(19) United States
(12) Patent Application Publication
(10) Pub. No.: US 2023/0106317 A1
(43) Pub. Date: Apr. 6, 2023

(54) POLYCYCLIC COMPOUND AND ORGANIC LIGHT-EMITTING ELEMENT COMPRISING SAME

(71) Applicant: LG CHEM, LTD., Seoul (KR)

(72) Inventors: Moung Gon KIM, Daejeon (KR); Sujeong GEUM, Daejeon (KR); Kyunghee KIM, Daejeon (KR); Hojung LEE, Daejeon (KR); Woochul LEE, Daejeon (KR); Dongkeun SONG, Daejeon (KR)

(21) Appl. No.: 17/612,681

(22) PCT Filed: Nov. 27, 2020
(86) PCT No.: PCT/KR2020/017163

§ 371 Date: Nov. 19, 2021

(30) Foreign Application Priority Data
Nov. 29, 2019 (KR) 10-2019-0156843
Nov. 29, 2019 (KR) 10-2019-0157427
Sep. 18, 2020 (KR) 10-2020-0120556

(51) Int. Cl. H01L 51/00; C07F 5/02; C09K 11/06

(52) U.S. Cl. CPC H01L 51/008; C07F 5/027; H01L 51/0073; H01L 51/5012; C09K 11/06; C09K 2211/1018; H01L 51/0058

(57) ABSTRACT

Provided is a polycyclic compound of Chemical Formula 1:

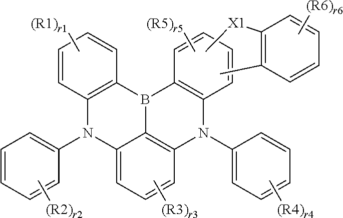

wherein:
   X1 is O, S, or CR7R8;
   R1 to R8 each independently is hydrogen, deuterium, a cyano group, a halogen group, or a substituted or unsubstituted alkyl, alkoxy, alkylthio, cycloalkyl, silyl, aryl, aryloxy, arylthio, heterocyclic, or amine group, or bond to adjacent substituents to form a substituted or unsubstituted ring;
   one or more of R1 to R6 bond to adjacent substituents to form a substituted or unsubstituted aliphatic hydrocarbon ring;
   r1 and r6 are an integer of 0-4, r3 is an integer of 0-3, r2 and r4 are an integer of 0-5, and r5 is an integer of 0-2;
   r1+r2+r3+r4+r5+r6 is ≥2; and
   when r1 to r4 and r6 are each ≥2 or r5=2, substituents in the parentheses are the same as or different from each other,
      and an organic light-emitting device including the same.

### CROSS-REFERENCE TO RELATED APPLICATIONS

This application is a National Stage Application of International Application No. PCT/KR2020/017163 filed on Nov. 27, 2020, which claims priority to and the benefits of Korean Patent Application No. 10-2019-0157427, filed with the Korean Intellectual Property Office on Nov. 29, 2019; Korean Patent Application No. 10-2019-0156843, filed with the Korean Intellectual Property Office on Nov. 29, 2019; and Korean Patent Application No. 10-2020-0120556, filed with the Korean Intellectual Property Office on Sep. 18, 2020, the entire contents of which are incorporated herein by reference.

### TECHNICAL FIELD

The present specification relates to a polycyclic compound, and an organic light emitting device including the same.

### BACKGROUND

An organic light emitting device in the present specification is a light emitting device using an organic semiconductor material, and requires an exchange of holes and/or electrons between an electrode and the organic semiconductor material. An organic light emitting device can be largely divided into two types as follows depending on the operation principle. The first is a light emitting device type in which excitons are formed in an organic material layer by photons introduced to a device from an external light source, these excitons are separated into electrons and holes, and these electrons and holes are each transferred to different electrodes and used as a current source (voltage source). The second is a light emitting device type in which, by applying a voltage or current to two or more electrodes, holes and/or electrons are injected into an organic semiconductor material layer forming an interface with the electrodes, and the light emitting device is operated by the injected electrons and holes.

An organic light emission phenomenon generally refers to a phenomenon converting electrical energy to light energy using an organic material. An organic light emitting device using an organic light emission phenomenon normally has a structure including an anode, a cathode, and an organic material layer therebetween. Herein, the organic material layer is often formed in a multilayer structure formed with different materials in order to increase efficiency and stability of the organic light emitting device, and for example, can be formed with a hole injection layer, a hole transfer layer, a light emitting layer, an electron blocking layer, an electron transfer layer, an electron injection layer and the like. When a voltage is applied between the two electrodes in such an organic light emitting device structure, holes and electrons are injected to the organic material layer from the anode and the cathode, respectively, and when the injected holes and electrons meet, excitons are formed, and light emits when these excitons fall back to the ground state. Such an organic light emitting device is known to have properties such as self-emission, high luminance, high efficiency, low driving voltage, wide viewing angle and high contrast.

Materials used as an organic material layer in an organic light emitting device can be divided into a light emitting material and a charge transfer material, for example, a hole injection material, a hole transfer material, an electron blocking material, an electron transfer material, an electron injection material and the like depending on the function. The light emitting material includes, depending on light emitting color, blue, green and red light emitting materials, and yellow and orange light emitting materials required for obtaining better natural colors.

In addition, in order to increase color purity and light emission efficiency through energy transition, a host/dopant-based can be used as the light emitting material. The principle is that light with high efficiency is produced when mixing a small amount of dopant having a smaller energy band gap and superior light emission efficiency compared to a host mainly consisting a light emitting layer into the light emitting layer by the transferring of excitons produced in the host to the dopant. Herein, the wavelength of the host is shifted to the wavelength band of the dopant, and therefore, light with a target wavelength can be obtained depending on the types of the dopant used.

In order to sufficiently exhibit excellent properties that the above-described organic light emitting device has, materials forming an organic material layer in the device, for example, a hole injection material, a hole transfer material, a light emitting material, an electron blocking material, an electron transfer material, an electron injection material and the like are supported by stable and efficient materials, and therefore, development of new materials has been continuously required.

Prior Art Documents (Patent Document 1) International Patent Application Laid-Open Publication No. 2016-152418

### BRIEF DESCRIPTION

### Technical Problem

The present specification describes a polycyclic compound, and an organic light emitting device including the same.

### Technical Solution

One embodiment of the present specification provides a polycyclic compound of the following Chemical Formula 1:

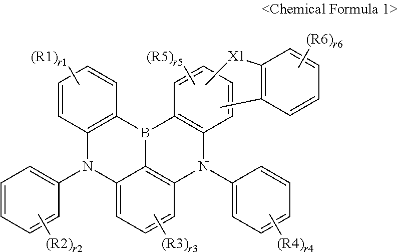

wherein in Chemical Formula 1:

X1 is O, S, or CR7R8;

R1 to R8 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring;

one or more of R1 to R6 bond to adjacent substituents to form a substituted or unsubstituted aliphatic hydrocarbon ring;

r1 and r6 are an integer of 0 to 4, r3 is an integer of 0 to 3, r2 and r4 are an integer of 0 to 5, and r5 is an integer of 0 to 2;

r1+r2+r3+r4+r5+r6 is 2 or greater; and when r1 to r4 and r6 are each 2 or greater or r5 is 2, the substituents in the parentheses are the same as or different from each other.

Another embodiment of the present disclosure provides an organic light emitting device including a first electrode; a second electrode provided opposite to the first electrode; and one or more organic material layers provided between the first electrode and the second electrode, wherein one or more layers of the organic material layers include the polycyclic compound described above.

### Advantageous Effects

A compound of the present disclosure can be used as a material of an organic material layer of an organic light emitting device. When manufacturing an organic light emitting device including the compound of the present disclosure, an organic light emitting device having properties of high efficiency, low voltage and long lifetime can be obtained, and when including the compound of the present disclosure in a light emitting layer of an organic light emitting device, an organic light emitting device having high color gamut can be manufactured.

### DESCRIPTION OF THE DRAWINGS

FIG. 1 and FIG. 2 illustrate examples of an organic light emitting device according to the present disclosure.

### REFERENCE NUMERALS

1: Substrate
2: Anode
3: Light Emitting Layer
4: Cathode
5: First Hole Injection Layer
6: Second Hole Injection Layer
7: Hole Transfer Layer
8: Electron Blocking Layer
9: First Electron Transfer Layer
10: Second Electron Transfer Layer
11: Electron Injection Layer

### DETAILED DESCRIPTION

Hereinafter, the present specification will be described in more detail.

One embodiment of the present specification provides a polycyclic compound of Chemical Formula 1. Specifically, when using the polycyclic compound of Chemical Formula 1 in an organic material layer of an organic light emitting device, efficiency and lifetime properties of the organic light emitting device are enhanced. Particularly, existing compounds having a high sublimation temperature have low compound stability, and have had a problem of reducing device efficiency and lifetime when used in a device, however, by including Chemical Formula A in the molecule, the compound of Chemical Formula 1 has high stability by having a low sublimation temperature, and as a result, a device having superior efficiency and long lifetime properties can be obtained when using the compound of Chemical Formula 1 in a device.

In addition, by including an aliphatic hydrocarbon ring (specifically, a cycloalkyl ring, a cycloalkene ring) in the molecule, the polycyclic compound of Chemical Formula 1 has increased solubility, and can also be used for a solution process.

In the present specification, a description of a certain part “including” certain constituents means capable of further including other constituents, and does not exclude other constituents unless particularly stated on the contrary.

In the present specification, a description of one member being placed “on” another member includes not only a case of the one member being in contact with the another member but a case of still another member being present between the two members.

In the present specification, * or a dotted line means a site bonding or fused to other substituents or bonding sites.

In the present specification, Cn means that the number of carbon atoms is n, and Cn-Cm means that the number of carbon atoms is from n to m.

Examples of substituents in the present specification are described below, however, the substituents are not limited thereto.

The term “substitution” means a hydrogen atom bonding to a carbon atom of a compound being changed to another substituent, and the position of substitution is not limited as long as it is a position at which a hydrogen atom is substituted, that is, a position at which a substituent can substitute, and when two or more substituents substitute, the two or more substituents can be the same as or different from each other.

In the present specification, a term “substituted or unsubstituted” means being substituted with one, two or more substituents selected from the group consisting of deuterium, a halogen group, a cyano group (—CN), a silyl group, a boron group, an alkyl group, a cycloalkyl group, an aryl group, a fused hydrocarbon ring group, a heterocyclic group, and an amine group, or being substituted with a substituent linking two or more substituents among the substituents illustrated above, or having no substituents. For example, “a substituent linking two or more substituents” can include a biphenyl group. In other words, a biphenyl group can be an aryl group, or interpreted as a substituent linking two phenyl groups.

In one embodiment of the present specification, “substituted or unsubstituted” means being substituted with one or more substituents selected from the group consisting of deuterium, a halogen group, a cyano group (—CN), a silyl group, a C1-C20 alkyl group, a C3-C60 cycloalkyl group, a C6-C60 aryl group, a C9-C60 fused hydrocarbon ring group, a C2-C60 heterocyclic group, and an amine group, or being substituted with a substituent linking two or more substituents selected from the above-described group, or having no substituents.

In one embodiment of the present specification, “substituted or unsubstituted” means being substituted with one or more substituents selected from the group consisting of deuterium, a halogen group, a cyano group (—CN), a silyl group, a C1-C10 alkyl group, a C3-C30 cycloalkyl group, a C6-C30 aryl group, a C9-C30 fused hydrocarbon ring group, a C2-C30 heterocyclic group, and an amine group, or being substituted with a substituent linking two or more substituents selected from the above-described group, or having no substituents.

In one embodiment of the present specification, “substituted or unsubstituted” means being substituted with one or more substituents selected from the group consisting of deuterium, a halogen group, a cyano group (—CN), a silyl group, a C1-C6 alkyl group, a C3-C20 cycloalkyl group, a C6-C20 aryl group, a C9-C20 fused hydrocarbon ring group, a C2-C20 heterocyclic group, and an amine group, or being substituted with a substituent linking two or more substituents selected from the above-described group, or having no substituents.

In the present specification, linking two or more substituents refers to replacing hydrogen of any one substituent with another substituent. For example, an isopropyl group and a phenyl group can be linked to become a substituent of

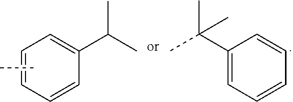

In the present specification, linking three substituents includes not only continuously linking (substituent 1)-(substituent 2)-(substituent 3), but also linking (substituent 2) and (substituent 3) to (substituent 1). For example, two phenyl groups and an isopropyl group can be linked to become a substituent of

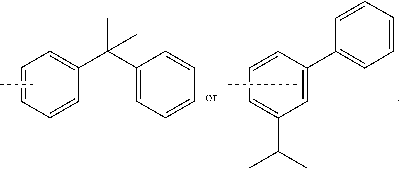

The same rule described above also applies to linking four or more substituents.

In the present specification, “substituted with A or B” includes not only a case of being substituted with only A or substituted with only B, but also a case of being substituted with A and B.

Examples of the substituents are described below, however, the substituents are not limited thereto.

In the present specification, examples of the halogen group can include fluorine (F), chlorine (Cl), bromine (Br) or iodine (I).

In the present specification, the silyl group can be a chemical formula of —SiY₁₁Y₁₂Y₁₃, and Y₁₁, Y₁₂ and Y₁₃ can each be hydrogen, a substituted or unsubstituted alkyl group, or a substituted or unsubstituted aryl group. Specific examples of the silyl group can include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but are not limited thereto.

In the present specification, the boron group can be a chemical formula of —BY₁₄Y₁₅, and Y₁₄ and Y₁₅ can each be hydrogen, a substituted or unsubstituted alkyl group, or a substituted or unsubstituted aryl group. Specific examples of the boron group can include a trimethylboron group, a triethylboron group, a t-butyldimethylboron group, a triphenylboron group, a phenylboron group and the like, but are not limited thereto.

In the present specification, the alkyl group can be linear or branched, and although not particularly limited thereto, the number of carbon atoms is preferably from 1 to 60. According to one embodiment, the number of carbon atoms of the alkyl group is from 1 to 30. According to another embodiment, the number of carbon atoms of the alkyl group is from 1 to 20. According to another embodiment, the number of carbon atoms of the alkyl group is from 1 to 10. According to another embodiment, the number of carbon atoms of the alkyl group is from 1 to 6. According to another embodiment, the number of carbon atoms of the alkyl group is from 1 to 4. Specific examples of the alkyl group can include a methyl group, an ethyl group, a propyl group, an isopropyl group, a butyl group, an isobutyl group, a tert-butyl group, a pentyl group, a hexyl group, a heptyl group, an octyl group and the like, but are not limited thereto.

In the present specification, the alkoxy group means linking an alkyl group to an oxygen atom, and the alkylthio group means linking an alkyl group to a sulfur atom, and as the alkyl group in the alkoxy group and the alkylthio group, the description on the alkyl group provided above can be applied.

In the present specification, the amine group can be selected from the group consisting of —NH₂, an alkylamine group, an alkylarylamine group, an arylamine group, an arylheteroarylamine group, an alkylheteroarylamine group, and a heteroarylamine group, and although not particularly limited thereto, the number of carbon atoms is preferably from 1 to 60. In the arylamine group, the number of carbon atoms is from 6 to 60. According to another embodiment, the number of carbon atoms of the arylamine group is from 6 to 40. Specific examples of the amine group can include a methylamine group, a dimethylamine group, an ethylamine group, a diethylamine group, a phenylamine group, a naphthylamine group, a biphenylamine group, an anthracenylamine group, a 9-methylanthracenylamine group, a diphenylamine group, an N-phenylnaphthylamine group, a ditolylamine group, an N-phenyltolylamine group, a triphenylamine group, an N-phenylbiphenylamine group, an N-phenylnaphthylamine group, an N-biphenylnaphthylamine group, an N-naphthylfluorenylamine group, an N-phenylphenanthrenylamine group, an N-biphenylphenanthrenylamine group, an N-phenylfluorenylamine group, an N-phenylterphenylamine group, an N-phenanthrenylfluorenylamine group, an N-biphenylfluorenylamine group, an N-(4-(tert-butyl)phenyl)-N-phenylamine group, an N,N-bis(4-(tert-butyl)phenyl)amine group, an N,N-bis(3-(tert-butyl)phenyl)amine group, and the like, but are not limited thereto.

In the present specification, the alkylamine group means an amine group in which N of the amine group is substituted with an alkyl group, and includes a dialkylamine group, an alkylarylamine group and an alkylheteroarylamine group.

In the present specification, the arylamine group means an amine group in which N of the amine group is substituted with aryl group, and includes a diarylamine group, an arylheteroarylamine group and an alkylarylamine group.

In the present specification, the heteroarylamine group means an amine group in which N of the amine group is substituted with a heteroaryl group, and includes a diheteroarylamine group, an arylheteroarylamine group and an alkylheteroarylamine group.

In the present specification, the alkylarylamine group means an amine group in which N of the amine group is substituted with an alkyl group and an aryl group.

In the present specification, the arylheteroarylamine group means an amine group in which N of the amine group is substituted with an aryl group and a heteroaryl group.

In the present specification, the alkylheteroarylamine group means an amine group in which N of the amine group is substituted with an alkyl group and a heteroaryl group.

In the present specification, the alkyl group in the alkylamine group, the arylalkylamine group, the alkylthioxy group, the alkylsulfoxy group and the alkylheteroarylamine group is the same as the examples of the alkyl group. Specific examples of the alkylthioxy group can include a methylthioxy group, an ethylthioxy group, a tert-butylthioxy group, a hexylthioxy group, an octylthioxy group, and the like, and specific examples of the alkylsulfoxy group can include mesyl, an ethylsulfoxy group, a propylsulfoxy group, a butylsulfoxy group, and the like, however, the alkylthioxy group and the alkylsulfoxy group are not limited thereto.

In the present specification, the cycloalkyl group is not particularly limited, but preferably has 3 to 60 carbon atoms, and according to one embodiment, the number of carbon atoms of the cycloalkyl group is from 3 to 30. According to another embodiment, the number of carbon atoms of the cycloalkyl group is from 3 to 20. According to another embodiment, the number of carbon atoms of the cycloalkyl group is from 3 to 6. The cycloalkyl group includes not only a monocyclic group, but also a bicyclic group such as a bridgehead, a fused ring or a spiro ring. Specific examples thereof can include a cyclopropyl group, a cyclobutyl group, a cyclopentyl group, a cyclohexyl group, a cycloheptyl group, a cyclooctyl group, an adamantyl group, and the like, but are not limited thereto.

In the present specification, the cycloalkene is a cyclic group that has a double bond present in the hydrocarbon ring but is not aromatic, and although not particularly limited thereto, the number of carbon atoms can be from 3 to 60, and according to one embodiment, the number of carbon atoms can be from 3 to 30. The cycloalkene includes not only a monocyclic group, but also a bicyclic group such as a bridgehead, a fused ring or a spiro ring. Examples of the cycloalkene can include cyclopropene, cyclobutene, cyclopentene, cyclohexene, and the like, but are not limited thereto.

In the present specification, the aryl group is not particularly limited, but preferably has 6 to 60 carbon atoms, and can be a monocyclic aryl group or a polycyclic aryl group. According to one embodiment, the number of carbon atoms of the aryl group is from 6 to 30. According to one embodiment, the number of carbon atoms of the aryl group is from 6 to 20. When the aryl group is a monocyclic aryl group, examples thereof can include a phenyl group, a biphenyl group, a terphenyl group, and the like, but are not limited thereto. Examples of the polycyclic aryl group can include a naphthyl group, an anthracenyl group, a phenanthrenyl group, a pyrenyl group, a perylenyl group, a triphenyl group, a chrysenyl group, a fluorenyl group, and the like, but are not limited thereto.

In the present specification, a No. 9 carbon atom (C) of the fluorenyl group can be substituted with an alkyl group, an aryl group, and the like, and two substituents can bond to each other to form cyclopentane and a spiro structure such as fluorene.

In the present specification, the substituted aryl group can also include a form in which an aliphatic ring is fused to the aryl group. For example, a tetrahydronaphthalene group, a dihydroindene group and a dihydroanthracene group of the following structures are included in the substituted aryl group. In the following structures, one of the carbons of the benzene ring can be linked to other positions:

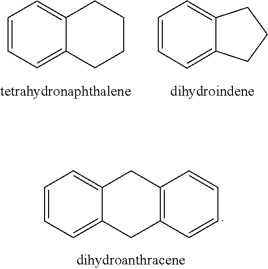

In the present specification, the fused hydrocarbon ring group means a fused ring group of aromatic hydrocarbon ring and aliphatic hydrocarbon ring, and has a form in which the aromatic hydrocarbon ring and the aliphatic hydrocarbon ring are fused. The fused hydrocarbon ring group has 9 to 60, 9 to 30, 9 to 20, or 9 to 10 carbon atoms. Examples of the fused ring group of aromatic hydrocarbon ring and aliphatic hydrocarbon ring can include a tetrahydronaphthalene group, a dihydroindene group and a dihydroanthracene group, but are not limited thereto.

In the present specification, the alkylaryl group means an aryl group substituted with an alkyl group, and can have substituents other than the alkyl group additionally linked thereto.

In the present specification, the arylalkyl group means an alkyl group substituted with an aryl group, and can have substituents other than the aryl group additionally linked thereto.

In the present specification, the aryloxy group means linking an aryl group to an oxygen atom, and the arylthio group means linking an aryl group to a sulfur atom, and as the aryl group in the aryloxy group and the arylthio group, the descriptions on the aryl group provided above can be applied. The aryl group in the aryloxy group is the same as the examples of the aryl group described above. Specific examples of the aryloxy group can include a phenoxy group, a p-tolyloxy group, an m-tolyloxy group, a 3,5-dimethyl-phenoxy group, a 2,4,6-trimethylphenoxy group, a p-tert-butylphenoxy group, a 3-biphenyloxy group, a 4-biphenyloxy group, a 1-naphthyloxy group, a 2-naphthyloxy group, a 4-methyl-1-naphthyloxy group, a 5-methyl-2-naphthyloxy group, a 1-anthryloxy group, a 2-anthryloxy group, a 9-anthryloxy group, a 1-phenanthryloxy group, a 3-phenanthryloxy group, a 9-phenanthryloxy group and the like, and examples of the arylthioxy group can include a phenylthioxy group, a 2-methylphenylthioxy group, a 4-tert-butylphenylthioxy group, and the like, however, the aryloxy group and the arylthioxy group are not limited thereto.

In the present specification, the heterocyclic group is a cyclic group including one or more of N, O, P, S, Si and Se as a heteroatom, and although not particularly limited thereto, the number of carbon atoms is preferably from 2 to 60. According to one embodiment, the number of carbon atoms of the heterocyclic group is from 2 to 30. According to one embodiment, the number of carbon atoms of the heterocyclic group is from 2 to 20. Examples of the heterocyclic group can include a pyridyl group, a quinoline group, a thiophene group, a dibenzothiophene group, a furan group, a dibenzofuran group, a naphthobenzofuran group, a carbazole group, a benzocarbazole group, a naphthobenzothiophene group, a dibenzosilole group, a naphthobenzosilole group, a hexahydrocarbazole group, a dihydroacridine group, a dihydrodibenzoazasiline group, a phenoxazine group, a phenothiazine group, a dihydrodibenzoazasiline group, a spiro(dibenzosilole-dibenzoazasiline) group, a spiro(acridine-fluorene) group, and the like, but are not limited thereto:

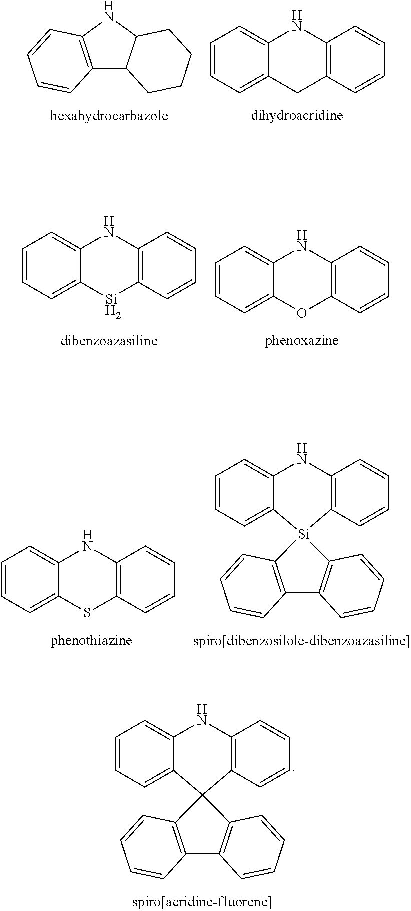

In the present specification, the descriptions on the heterocyclic group provided above can be applied to the heteroaryl group except for being aromatic.

In the present specification, the aromatic hydrocarbon ring means a hydrocarbon ring having pi electrons completely conjugated and planar, and the descriptions on the aryl group provided above can be applied thereto except for those that are divalent. The number of carbon atoms of the aromatic hydrocarbon ring can be from 6 to 60; 6 to 30; 6 to 20; or 6 to 10.

In the present specification, the aliphatic hydrocarbon ring has a structure bonding in a ring shape, and means a ring that is not aromatic. Examples of the aliphatic hydrocarbon ring can include cycloalkyl or cycloalkene, and the descriptions on the cycloalkyl group or the cycloalkenyl group can be applied thereto except for those that are divalent. The number of carbon atoms of the aliphatic hydrocarbon ring can be from 3 to 60, 3 to 30, 3 to 20, 3 to 10, 5 to 50, 5 to 30, 5 to 20, 5 to 10, or 5 to 6. In addition, the substituted aliphatic hydrocarbon ring also includes an aliphatic hydrocarbon ring to which an aromatic ring is fused.

In the present specification, the “adjacent” group can mean a substituent substituting an atom directly linked to an atom substituted by the corresponding substituent, a substituent sterically most closely positioned to the corresponding substituent, or another substituent substituting an atom substituted by the corresponding substituent. For example, two substituents substituting ortho positions in a benzene ring, and two substituents substituting the same carbon in an aliphatic ring can be interpreted as groups “adjacent” to each other. In addition, substituents linked to consecutive two carbons in the aliphatic ring (total of 4) can also be interpreted as groups “adjacent” to each other.

In the present specification, the meaning of “adjacent groups bonding to each other to form a ring” among the substituents is bonding to adjacent groups to form a substituted or unsubstituted hydrocarbon ring, or a substituted or unsubstituted heteroring.

In the present specification, a “5-membered or 6-membered ring formed by adjacent groups bonding to each other” means a ring including substituents participating in the ring formation being 5-membered or 6-membered. It includes an additional ring being fused to the ring including substituents participating in the ring formation.

In the present specification, when substituents of an aromatic hydrocarbon ring or an aryl group bond to adjacent substituents to form an aliphatic hydrocarbon ring, the aliphatic hydrocarbon ring includes two pi electrons (carbon-carbon double bond) of the aromatic hydrocarbon ring or the aryl group even when the double bond is not specified.

In the present specification, the descriptions on the aryl group provided above can be applied to the arylene group except for being a divalent group.

One embodiment of the present specification provides a polycyclic compound of Chemical Formula 1:

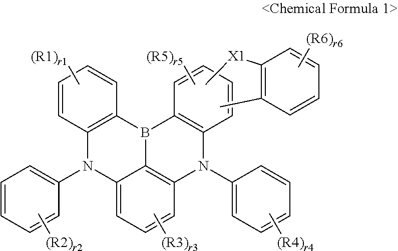

wherein in Chemical Formula 1:

X1 is O, S, or CR7R8;

R1 to R8 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring;

one or more of R1 to R6 bond to adjacent substituents to form a substituted or unsubstituted aliphatic hydrocarbon ring;

r1 and r6 are an integer of 0 to 4, r3 is an integer of 0 to 3, r2 and r4 are an integer of 0 to 5, and r5 is an integer of 0 to 2;

r1+r2+r3+r4+r5+r6 is 2 or greater; and when r1 to r4 and r6 are each 2 or greater or r5 is 2, the substituents in the parentheses are the same as or different from each other.

In one embodiment of the present specification, X1 is O or S.

In one embodiment of the present specification, X1 is

CR7R8.

In one embodiment of the present specification,

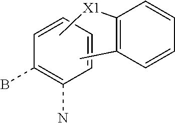

of Chemical Formula 1 is selected from among the following structures:

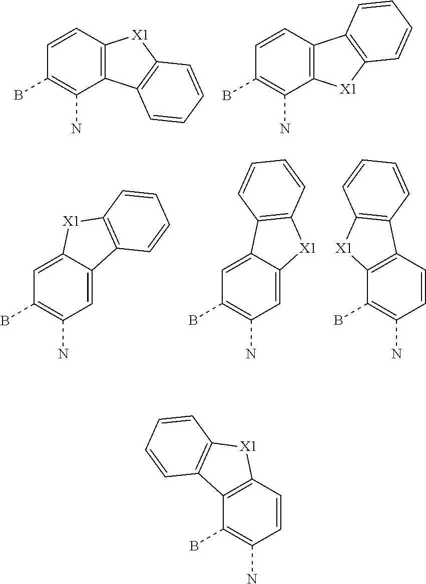

wherein in the structures, a dotted line is a site fused to Chemical Formula 1.

In one embodiment of the present specification, Chemical Formula 1 is any one of the following Chemical Formulae 2 to 6:

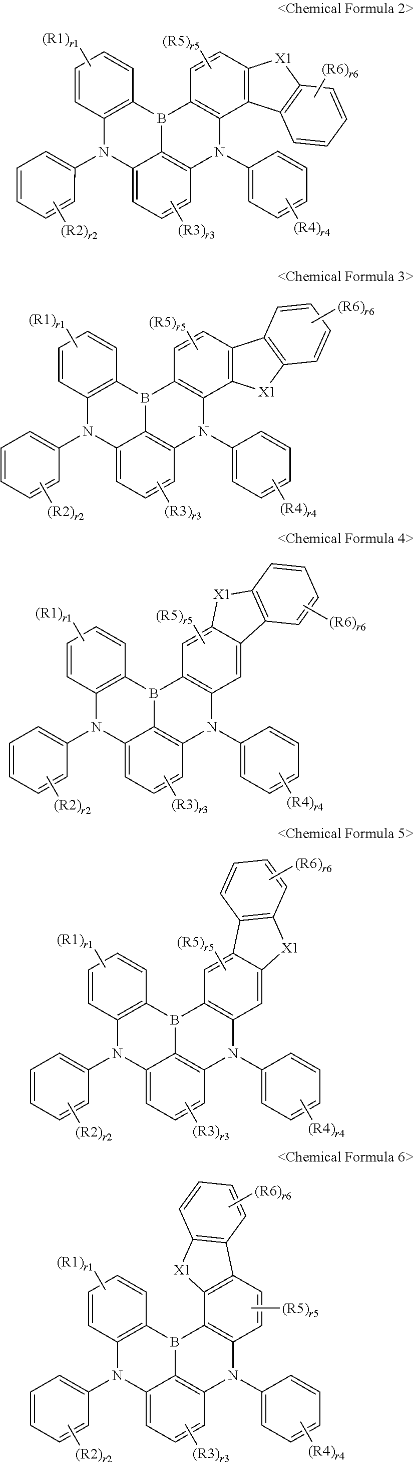

wherein in Chemical Formulae 2 to 6:

X1, R1 to R6 and r1 to r6 have the same definitions as in Chemical Formula 1.

In one embodiment of the present specification, R1 to R5 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring.

In one embodiment of the present specification, R1 to R6 are the same as or different from each other, and each independently is hydrogen, deuterium, a cyano group, a halogen group, a substituted or unsubstituted C1-C10 alkyl group, a substituted or unsubstituted C1-C10 alkoxy group, a substituted or unsubstituted C1-C10 alkylthio group, a substituted or unsubstituted C3-C30 cycloalkyl group, a substituted or unsubstituted silyl group, a substituted or unsubstituted C6-C30 aryl group, a substituted or unsubstituted C6-C30 aryloxy group, a substituted or unsubstituted C6-C30 arylthio group, a substituted or unsubstituted C2-C30 heterocyclic group, or a substituted or unsubstituted amine group, or bond to adjacent substituents to form a substituted or unsubstituted C2-C30 ring.

In one embodiment of the present specification, R1 to R6 are the same as or different from each other, and each independently is hydrogen, deuterium, a cyano group, a halogen group, a substituted or unsubstituted C1-C6 alkyl group, a substituted or unsubstituted C1-C6 alkoxy group, a substituted or unsubstituted C1-C6 alkylthio group, a substituted or unsubstituted C3-C20 cycloalkyl group, a substituted or unsubstituted silyl group, a substituted or unsubstituted C6-C20 aryl group, a substituted or unsubstituted C6-C20 aryloxy group, a substituted or unsubstituted C6-C20 arylthio group, a substituted or unsubstituted C2-C20 heterocyclic group, or a substituted or unsubstituted amine group, or bond to adjacent substituents to form a substituted or unsubstituted C2-C20 ring.

In one embodiment of the present specification, R1 to R6 are the same as or different from each other, and each independently is hydrogen, deuterium, a cyano group, a halogen group, a substituted or unsubstituted C1-C10 alkyl group, a substituted or unsubstituted C1-C10 alkoxy group, a substituted or unsubstituted C1-C10 alkylthio group, a substituted or unsubstituted C3-C30 cycloalkyl group, a substituted or unsubstituted C1-C30 alkylsilyl group, a substituted or unsubstituted C6-C90 arylsilyl group, a substituted or unsubstituted C6-C30 aryl group, a substituted or unsubstituted C6-C30 aryloxy group, a substituted or unsubstituted C6-C30 arylthio group, a substituted or unsubstituted C2-C30 heterocyclic group, a substituted or unsubstituted C1-C30 alkylamine group, a substituted or unsubstituted C6-C60 arylamine group, or a substituted or unsubstituted C2-C60 heteroarylamine group, or bond to adjacent substituents to form a substituted or unsubstituted C2-C30 ring.

In one embodiment of the present specification, R1 to R6 are the same as or different from each other, and each independently is hydrogen, deuterium, a cyano group, a halogen group, a substituted or unsubstituted C1-C6 alkyl group, a substituted or unsubstituted C1-C6 alkoxy group, a substituted or unsubstituted C1-C6 alkylthio group, a substituted or unsubstituted C3-C20 cycloalkyl group, a substituted or unsubstituted C1-C18 alkylsilyl group, a substituted or unsubstituted C6-C60 arylsilyl group, a substituted or unsubstituted C6-C20 aryl group, a substituted or unsubstituted C6-C20 aryloxy group, a substituted or unsubstituted C6-C20 arylthio group, a substituted or unsubstituted C2-C20 heterocyclic group, a substituted or unsubstituted C1-C18 alkylamine group, a substituted or unsubstituted C6-C40 arylamine group, or a substituted or unsubstituted C2-C40 heteroarylamine group, or bond to adjacent substituents to form a substituted or unsubstituted C2-C20 ring.

In one embodiment of the present specification, R1 to R6 are the same as or different from each other, and each independently is hydrogen; deuterium; an alkyl group that is unsubstituted or substituted with deuterium; a cycloalkyl group; an aryl group that is unsubstituted or substituted with one or more substituents selected from the group consisting of deuterium and an alkyl group, or a substituent linking two or more groups selected from the above-described group; or an amine group that is unsubstituted or substituted with one or more substituents selected from the group consisting of deuterium, an alkyl group, an aryl group, a fused ring group of aromatic hydrocarbon ring and aliphatic hydrocarbon ring, and a heterocyclic group, or a substituent linking two or more groups selected from the above-described group, or bond to adjacent substituents to form a hydrocarbon ring or heteroring that is unsubstituted or substituted with one or more substituents selected from the group consisting of deuterium and an alkyl group, or a substituent linking two or more groups selected from the above-described group.

In one embodiment of the present specification, R1 to R6 are the same as or different from each other, and each independently is hydrogen; deuterium; an alkyl group that is unsubstituted or substituted with deuterium; a cycloalkyl group; an aryl group that is unsubstituted or substituted with one or more substituents selected from the group consisting of deuterium and an alkyl group, or a substituent linking two or more groups selected from the above-described group; or an amine group that is unsubstituted or substituted with one or more substituents selected from the group consisting of deuterium, an alkyl group, an aryl group, a fused ring group of aromatic hydrocarbon ring and aliphatic hydrocarbon ring, and a heterocyclic group, or a substituent linking two or more groups selected from the above-described group, or bond to adjacent substituents to form a hydrocarbon ring or heteroring that is unsubstituted or substituted with one or more substituents selected from the group consisting of deuterium and an alkyl group, or a substituent linking two or more groups selected from the above-described group,

The number of carbon atoms of the alkyl group is from 1 to 10, the number of carbon atoms of the cycloalkyl group and the aliphatic hydrocarbon ring is from 3 to 30, the number of carbon atoms of the aryl group and the aromatic hydrocarbon ring is from 6 to 30, the number of carbon atoms of the heteroring is from 2 to 30, and the heteroring includes one or more of N, O, S and Si as a heteroatom.

In one embodiment of the present specification, R1 to R6 are the same as or different from each other, and each independently is hydrogen; deuterium; a C1-C10 alkyl group that is unsubstituted or substituted with deuterium; a C3-C30 cycloalkyl group; a C6-C30 aryl group that is unsubstituted or substituted with one or more substituents selected from the group consisting of deuterium and a C1-C10 alkyl group, or a substituent linking two or more groups selected from the above-described group; or an amine group that is unsubstituted or substituted with one or more substituents selected from the group consisting of deuterium, a C1-C10 alkyl group, a C6-C30 aryl group, a fused ring group of C6-C30 aromatic hydrocarbon ring and C3-C30 aliphatic hydrocarbon ring, and a C2-C30 heterocyclic group, or a substituent linking two or more groups selected from the above-described group, or bond to adjacent substituents to form a C5-C30 hydrocarbon ring or C2-C30 heteroring that is unsubstituted or substituted with one or more substituents selected from the group consisting of deuterium and a C1-C10 alkyl group, or a substituent linking two or more groups selected from the above-described group.

R1 to R6 bonding to adjacent substituents to form a ring refers to adjacent two R1s, adjacent two R2s, adjacent two R3s, adjacent two R4 s, adjacent two R5s, or adjacent two R6s bonding to each other to form a ring.

In one embodiment of the present specification, R1 to R6 bond to adjacent substituents to form a C5-C30 aliphatic hydrocarbon ring that is unsubstituted or substituted with a C1-C10 alkyl group, and not fused or fused with a C6-C30 aromatic hydrocarbon ring; a C2-C30 O-containing aromatic heteroring that is unsubstituted or substituted with a C1-C10 alkyl group; or a C2-C30 S-containing aromatic heteroring that is unsubstituted or substituted with a C1-C10 alkyl group.

In one embodiment of the present specification, R1 to R6 bond to adjacent substituents to form a ring of the following Chemical Formula Cy1; or a ring of the following Chemical Formula Cy2.

In one embodiment of the present specification, R1 to R6 bond to adjacent substituents to foil a cyclopentene ring that is unsubstituted or substituted with a methyl group; a cyclohexene ring that is unsubstituted or substituted with a methyl group; an indene ring that is unsubstituted or substituted with a methyl group; a tetrahydronaphthalene ring that is unsubstituted or substituted with a methyl group or a tert-butyl group; a benzofuran ring; or a benzothiophene ring.

In one embodiment of the present specification, R1 to R6 are the same as or different from each other, and each independently is hydrogen; deuterium; a C1-C6 alkyl group that is unsubstituted or substituted with deuterium; a C6-C20 aryl group that is unsubstituted or substituted with deuterium or a C1-C6 alkyl group; a C6-C40 arylamine group that is unsubstituted or substituted with deuterium, a C1-C6 alkyl group or a C2-C20 heterocyclic group and not fused or fused with a C5-C20 aliphatic hydrocarbon ring; or a C2-C40 heteroarylamine group that is unsubstituted or substituted with deuterium, a C1-05 alkyl group, a C6-C20 aryl group or a C7-C20 alkylaryl group, or bond to adjacent substituents to form a C5-C30 aliphatic hydrocarbon ring that is unsubstituted or substituted with a C1-C10 alkyl group and not fused or fused with a C6-C30 aromatic hydrocarbon ring; a C2-C30 O-containing aromatic heteroring; or a C2-C30 S-containing aromatic heteroring.

In one embodiment of the present specification, R1 to R6 are the same as or different from each other, and each independently is hydrogen; deuterium; a C1-C6 alkyl group that is unsubstituted or substituted with deuterium; a C6-C20 aryl group that is unsubstituted or substituted with deuterium or a C1-C6 alkyl group; a C6-C40 arylamine group that is unsubstituted or substituted with deuterium, a C1-C6 alkyl group or a C2-C20 heterocyclic group and not fused or fused with a C5-C20 aliphatic hydrocarbon ring; or a C2-C40 heteroarylamine group that is unsubstituted or substituted with deuterium, a C1-05 alkyl group, a C6-C20 aryl group or a C7-C20 alkylaryl group, or bond to adjacent substituents to form a ring of the following Chemical Formula Cy1; or a ring of the following Chemical Formula Cy2.

In one embodiment of the present specification, R1 to R6 are the same as or different from each other, and each independently is hydrogen; deuterium; a methyl group; an isopropyl group; a tert-butyl group; a cyclohexyl group; a phenyl group that is unsubstituted or substituted with a methyl group, an isopropyl group or a tert-butyl group; a biphenyl group; a diphenylamine group that is unsubstituted or substituted with a methyl group, an isopropyl group or a tert-butyl group; an N-phenylbiphenylamine group that is unsubstituted or substituted with a methyl group, an isopropyl group or a tert-butyl group; a dibiphenylamine group that is unsubstituted or substituted with a methyl group, an isopropyl group or a tert-butyl group; an N-phenylnaphthalenamine group that is unsubstituted or substituted with a methyl group, an isopropyl group or a tert-butyl group; an N-phenyltetrahydronaphthalenamine group that is unsubstituted or substituted with a methyl group, an isopropyl group or a tert-butyl group; an N-biphenyltetrahydronaphthalenamine group that is unsubstituted or substituted with a methyl group, an isopropyl group or a tert-butyl group; a bis(tetrahydronaphthalen)amine group that is unsubstituted or substituted with a methyl group, an isopropyl group or a tert-butyl group; an N-phenyldibenzofuranamine group that is unsubstituted or substituted with a methyl group, an isopropyl group or a tert-butyl group; or an N-phenyldibenzothiophenamine group that is unsubstituted or substituted with a methyl group, an isopropyl group or a tert-butyl group, or bond to adjacent substituents to form a cyclohexene ring that is unsubstituted or substituted with a methyl group, an isopropyl group or a tert-butyl group and not fused or fused with a benzene ring; a cyclopentene ring that is unsubstituted or substituted with a methyl group; an indene ring that is unsubstituted or substituted with a methyl group; a benzofuran ring; or a benzothiophene ring.

In one embodiment of the present specification, R3s are the same as or different from each other, and each independently is hydrogen, deuterium, a substituted or unsubstituted alkyl group, a substituted or unsubstituted cycloalkyl group, a substituted or unsubstituted aryl group, or a substituted or unsubstituted amine group.

In one embodiment of the present specification, R3 is hydrogen; deuterium; a C1-C10 alkyl group that is unsubstituted or substituted with deuterium; a C3-C30 cycloalkyl group; a C6-C30 aryl group that is unsubstituted or substituted with one or more substituents selected from the group consisting of deuterium and a C1-C10 alkyl group, or a substituent linking two or more groups selected from the above-described group; or an amine group that is unsubstituted or substituted with one or more substituents selected from the group consisting of deuterium, a C1-C10 alkyl group, a C6-C30 aryl group, a fused ring group of C6-C30 aromatic hydrocarbon ring and C3-C30 aliphatic hydrocarbon ring, and a C2-C30 heterocyclic group, or a substituent linking two or more groups selected from the above-described group.

In one embodiment of the present specification, R3 is hydrogen; deuterium; a C1-C6 alkyl group that is unsubstituted or substituted with deuterium; a C6-C20 aryl group that is unsubstituted or substituted with deuterium or a C1-C6 alkyl group; a C6-C40 arylamine group that is unsubstituted or substituted with deuterium, a C1-C6 alkyl group or a C2-C20 heterocyclic group and not fused or fused with a C5-C20 aliphatic hydrocarbon ring; or a C2-C40 heteroarylamine group that is unsubstituted or substituted with deuterium, a C1-05 alkyl group, a C6-C20 aryl group or a C7-C20 alkylaryl group.

In one embodiment of the present specification, R3 is hydrogen; deuterium; a methyl group; an isopropyl group; a tert-butyl group; a cyclohexyl group; a phenyl group that is unsubstituted or substituted with a methyl group, an isopropyl group or a tert-butyl group; a biphenyl group; a diphenylamine group that is unsubstituted or substituted with a methyl group, an isopropyl group or a tert-butyl group; an N-phenylbiphenylamine group that is unsubstituted or substituted with a methyl group, an isopropyl group or a tert-butyl group; a dibiphenylamine group that is unsubstituted or substituted with a methyl group, an isopropyl group or a tert-butyl group; an N-phenylnaphthalenamine group that is unsubstituted or substituted with a methyl group, an isopropyl group or a tert-butyl group; an N-phenyltetrahydronaphthalenamine group that is unsubstituted or substituted with a methyl group, an isopropyl group or a tert-butyl group; an N-biphenyltetrahydronaphthalenamine group that is unsubstituted or substituted with a methyl group, an isopropyl group or a tert-butyl group; a bis(tetrahydronaphthalen)amine group that is unsubstituted or substituted with a methyl group, an isopropyl group or a tert-butyl group; an N-phenyldibenzofuranamine group that is unsubstituted or substituted with a methyl group, an isopropyl group or a tert-butyl group; or an N-phenyldibenzothiophenamine group that is unsubstituted or substituted with a methyl group, an isopropyl group or a tert-butyl group.

In one embodiment of the present specification, R1 is hydrogen, deuterium, a substituted or unsubstituted alkyl group, a substituted or unsubstituted aryl group, or a substituted or unsubstituted amine group, or bonds to adjacent substituents to form a substituted or unsubstituted ring.

In one embodiment of the present specification, R1 is hydrogen; deuterium; a C1-C10 alkyl group that is unsubstituted or substituted with deuterium; a C6-C30 aryl group that is unsubstituted or substituted with one or more substituents selected from the group consisting of deuterium and a C1-C10 alkyl group, or a substituent linking two or more groups selected from the above-described group; or an amine group that is unsubstituted or substituted with one or more substituents selected from the group consisting of deuterium, a C1-C10 alkyl group, a C6-C30 aryl group, and a fused ring group of C6-C30 aromatic hydrocarbon ring and C3-C30 aliphatic hydrocarbon ring, or a substituent linking two or more groups selected from the above-described group, or bonds to adjacent substituents to form a ring of the following Cy1.

In one embodiment of the present specification, R1 is hydrogen; deuterium; a C1-C6 alkyl group that is unsubstituted or substituted with deuterium; a C6-C20 aryl group that is unsubstituted or substituted with deuterium or a C1-C6 alkyl group; or a C6-C40 arylamine group that is unsubstituted or substituted with deuterium or a C1-C6 alkyl group and not fused or fused with a C5-C20 aliphatic hydrocarbon ring, or bonds to adjacent substituents to form a ring of the following Cy1.

In one embodiment of the present specification, R1 is hydrogen; deuterium; a methyl group; an isopropyl group; a tert-butyl group; a cyclohexyl group; a phenyl group that is unsubstituted or substituted with a methyl group, an isopropyl group or a tert-butyl group; a biphenyl group; a diphenylamine group that is unsubstituted or substituted with a methyl group, an isopropyl group or a tert-butyl group; an N-phenylbiphenylamine group that is unsubstituted or substituted with a methyl group, an isopropyl group or a tert-butyl group; a dibiphenylamine group that is unsubstituted or substituted with a methyl group, an isopropyl group or a tert-butyl group; an N-phenylnaphthalenamine group that is unsubstituted or substituted with a methyl group, an isopropyl group or a tert-butyl group; an N-phenyltetrahydronaphthalenamine group that is unsubstituted or substituted with a methyl group, an isopropyl group or a tert-butyl group; an N-biphenyltetrahydronaphthalenamine group that is unsubstituted or substituted with a methyl group, an isopropyl group or a tert-butyl group; or a bis(tetrahydronaphthalen)amine group that is unsubstituted or substituted with a methyl group, an isopropyl group or a tert-butyl group, or bonds to adjacent substituents to form a cyclohexene ring that is unsubstituted or substituted with a methyl group, an isopropyl group or a tert-butyl group and not fused or fused with a benzene ring; or a cyclopentene ring that is unsubstituted or substituted with a methyl group.

In one embodiment of the present specification, R5 is hydrogen or deuterium.

In one embodiment of the present specification, R2 and R4 are the same as or different from each other, and each independently is hydrogen, deuterium, a substituted or unsubstituted alkyl group, or a substituted or unsubstituted aryl group, or bond to adjacent substituents to form a substituted or unsubstituted ring.

In one embodiment of the present specification, R2 and R4 are the same as or different from each other, and each independently is hydrogen; deuterium; a C1-C10 alkyl group that is unsubstituted or substituted with deuterium; or a C6-C30 aryl group that is unsubstituted or substituted with one or more substituents selected from the group consisting of deuterium and a C1-C10 alkyl group, or a substituent linking two or more groups selected from the above-described group, or bond to adjacent substituents to form a ring of the following Chemical Formula Cy1; or a ring of the following Chemical Formula Cy2.

In one embodiment of the present specification, R2 and R4 are the same as or different from each other, and each independently is hydrogen; deuterium; a C1-C6 alkyl group that is unsubstituted or substituted with deuterium; or a C6-C20 aryl group that is unsubstituted or substituted with deuterium or a C1-C6 alkyl group, or bond to adjacent substituents to form a ring of the following Chemical Formula Cy1; or a ring of the following Chemical Formula Cy2.

In one embodiment of the present specification, R2 and R4 are the same as or different from each other, and each independently is hydrogen; deuterium; a methyl group; an isopropyl group; a tert-butyl group; a cyclohexyl group; a phenyl group that is unsubstituted or substituted with a methyl group, an isopropyl group or a tert-butyl group; or a biphenyl group, or bond to adjacent substituents to form a cyclohexene ring that is unsubstituted or substituted with a methyl group, an isopropyl group or a tert-butyl group and not fused or fused with a benzene ring; a cyclopentene ring that is unsubstituted or substituted with a methyl group; an indene ring that is unsubstituted or substituted with a methyl group; a benzofuran ring; or a benzothiophene ring.

In one embodiment of the present specification, R2 is a substituent that is not hydrogen, and linked to an ortho position with respect to nitrogen (N). Specifically, to one or two of positions represented by a dotted line in the following formula, a substituent that is not hydrogen (R2 such as a halogen group, a cyano group, an alkyl group, an alkoxy group, an alkylthio group, an aryl group, an aryloxy group, an arylthio group, a heterocyclic group, a cycloalkyl group, an alkylsilyl group, an arylsilyl group, an arylalkyl group, an alkylamine group, an arylamine group or a heteroarylamine group) is linked. Herein, an additional substituent can also be linked to a meta or para position with respect to nitrogen (N), or a ring can be formed:

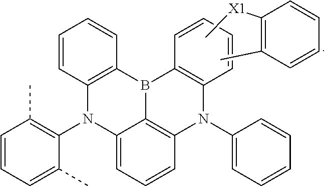

In one embodiment of the present specification, R4 is a substituent that is not hydrogen, and linked to an ortho position with respect to nitrogen (N). Specifically, to one or two of positions represented by a dotted line in the following formula, a substituent that is not hydrogen (R4 such as a halogen group, a cyano group, an alkyl group, an alkoxy group, an alkylthio group, an aryl group, an aryloxy group, an arylthio group, a heterocyclic group, a cycloalkyl group, an alkylsilyl group, an arylsilyl group, an arylalkyl group, an alkylamine group, an arylamine group or a heteroarylamine group) is linked. Herein, an additional substituent can also be linked to a meta or para position with respect to nitrogen (N), or a ring can be formed:

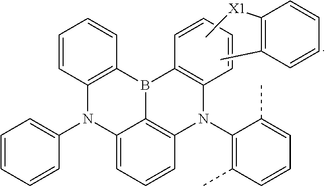

In one embodiment of the present specification, one or more of R1 to R6 bond to adjacent substituents to form a substituted or unsubstituted aliphatic hydrocarbon ring. Specifically, adjacent two R1s, adjacent two R2s, adjacent two R3s, adjacent two R4 s, adjacent two R5s, or adjacent two R6s bond to each other to form a substituted or unsubstituted aliphatic hydrocarbon ring (cycloalkyl ring or cycloalkene ring).

In one embodiment of the present specification, one or more of R1 to R6 bond to adjacent substituents to form a substituted or unsubstituted C5-C30 aliphatic hydrocarbon ring.

In one embodiment of the present specification, one or more of R1 to R6 bond to adjacent substituents to form a substituted or unsubstituted C5-C20 aliphatic hydrocarbon ring.

In one embodiment of the present specification, one or more of R1 to R6 bond to adjacent substituents to form an aliphatic hydrocarbon ring that is unsubstituted or substituted with an alkyl group and not fused or fused with an aromatic hydrocarbon ring.

In one embodiment of the present specification, one or more of R1 to R6 bond to adjacent substituents to form a C5-C30 aliphatic hydrocarbon ring that is unsubstituted or substituted with a C1-C10 alkyl group and not fused or fused with a C6-C30 aromatic hydrocarbon ring.

In one embodiment of the present specification, one or more of R1 to R6 bond to adjacent substituents to form a C5-C20 aliphatic hydrocarbon ring that is unsubstituted or substituted with a C1-C6 alkyl group and not fused or fused with a C6-C20 aromatic hydrocarbon ring.

In one embodiment of the present specification, one or more of R1 to R6 bond to adjacent substituents to form a cyclohexene ring that is unsubstituted or substituted with a methyl group or a tert-butyl group and not fused or fused with a benzene ring; or a cyclopentene ring that is unsubstituted or substituted with a methyl group.

In one embodiment of the present specification, one or more of R1, R2, R4 and R6 bond to adjacent substituents to form a substituted or unsubstituted aliphatic hydrocarbon ring.

In one embodiment of the present specification, one or more of r1 to r6 are 2 or greater.

In the present specification, when R1 bonds to adjacent substituents to form a substituted or unsubstituted ring, r1 is not 0. Specifically, when R1 bonds to adjacent R1 to form a substituted or unsubstituted ring, r1 is 2 or greater.

In the present specification, when R2 bonds to adjacent substituents to form a substituted or unsubstituted ring, r2 is not 0. Specifically, when R2 bonds to adjacent R2 to fain a substituted or unsubstituted ring, r2 is 2 or greater.

In the present specification, when R3 bonds to adjacent substituents to form a substituted or unsubstituted ring, r3 is not 0. Specifically, when R3 bonds to adjacent R3 to form a substituted or unsubstituted ring, r3 is 2 or greater.

In the present specification, when R4 bonds to adjacent substituents to form a substituted or unsubstituted ring, r4 is not 0. Specifically, when R4 bonds to adjacent R4 to form a substituted or unsubstituted ring, r4 is 2 or greater.

In the present specification, when R5 bonds to adjacent substituents to form a substituted or unsubstituted ring, r5 is not 0. Specifically, when R5 bonds to adjacent R5 to form a substituted or unsubstituted ring, r5 is 2 or greater.

In the present specification, when R6 bonds to adjacent substituents to form a substituted or unsubstituted ring, r1 is not 0. Specifically, when R6 bonds to adjacent R6 to form a substituted or unsubstituted ring, r6 is 2 or greater.

In one embodiment of the present specification, the substituted or unsubstituted aliphatic hydrocarbon ring formed by one or more of R1 to R6 bonding to adjacent substituents is the following Chemical Formula Cy1:

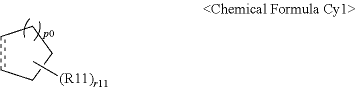

wherein in Chemical Formula Cy1:

a double dotted line is a position fused to Chemical Formula 1;

p0 is 1 or 2;

R11 is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bonds to adjacent substituents to form a substituted or unsubstituted ring; and r11 is an integer of 0 to 8, and when r11 is 2 or greater, the R11s are the same as or different from each other.

In one embodiment of the present specification, R11 is hydrogen, deuterium, or a substituted or unsubstituted C1-C10 alkyl group, or bonds to adjacent R11 to form a substituted or unsubstituted C6-C30 aromatic hydrocarbon ring.

In one embodiment of the present specification, R11 is hydrogen, deuterium, or a substituted or unsubstituted C1-C6 alkyl group, or bonds to adjacent R11 to form a substituted or unsubstituted C6-C20 aromatic hydrocarbon ring.

In one embodiment of the present specification, R11 is hydrogen, deuterium, or a C1-C10 alkyl group that is unsubstituted or substituted with deuterium, or bonds to adjacent R11 to form a C6-C30 aromatic hydrocarbon ring that is unsubstituted or substituted with deuterium or a C1-C10 alkyl group.

In one embodiment of the present specification, R11 is hydrogen, deuterium, or a substituted or unsubstituted methyl group, or bonds to adjacent R11 to form a benzene ring that is unsubstituted or substituted with a methyl group or a tert-butyl group.

In one embodiment of the present specification, two or four of R11s are a methyl group that is unsubstituted or substituted with deuterium.

In one embodiment of the present specification, two or four of R11s are a methyl group.

In one embodiment of the present specification, r11 is 2 or greater. In another embodiment, r11 is 2 or 4. In another embodiment, r11 is 8.

In one embodiment of the present specification, Chemical Formula Cy1 is selected from among the following structures:

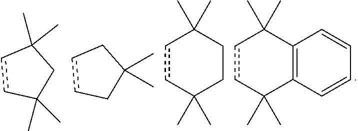

wherein in the structures, a double dotted line is a position fused to Chemical Formula 1.

In one embodiment of the present specification, R1 to R6 bond to adjacent substituents to form the ring of Chemical Formula Cy1, or a ring of the following Chemical Formula Cy2:

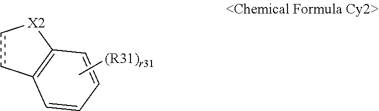

wherein in Chemical Formula Cy2:

X2 is O, S, or CR32R33;

R31 to R33 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring; and r31 is an integer of 0 to 4, and when r31 is 2 or greater, the R31s are the same as or different from each other.

In one embodiment of the present specification, R31 is hydrogen, deuterium, or a substituted or unsubstituted C1-C10 alkyl group, or bonds to adjacent R31 to form a substituted or unsubstituted C6-C30 aromatic hydrocarbon ring.

In one embodiment of the present specification, R31 is hydrogen, deuterium, or a substituted or unsubstituted methyl group, or bonds to adjacent R31 to form a benzene ring that is unsubstituted or substituted with a methyl group or a tert-butyl group.

In one embodiment of the present specification, R31 is hydrogen or deuterium.

In one embodiment of the present specification, R32 and R32 are the same as or different from each other, and each independently is a substituted or unsubstituted C1-C10 alkyl group or a substituted or unsubstituted C6-C30 aryl group, or bond to each other to form a substituted or unsubstituted C5-C30 ring.

In one embodiment of the present specification, R32 and R32 are the same as or different from each other, and each independently is a substituted or unsubstituted methyl group.

In one embodiment of the present specification, Chemical Formula 1 is any one of the following Chemical Formulae 101 to 104:

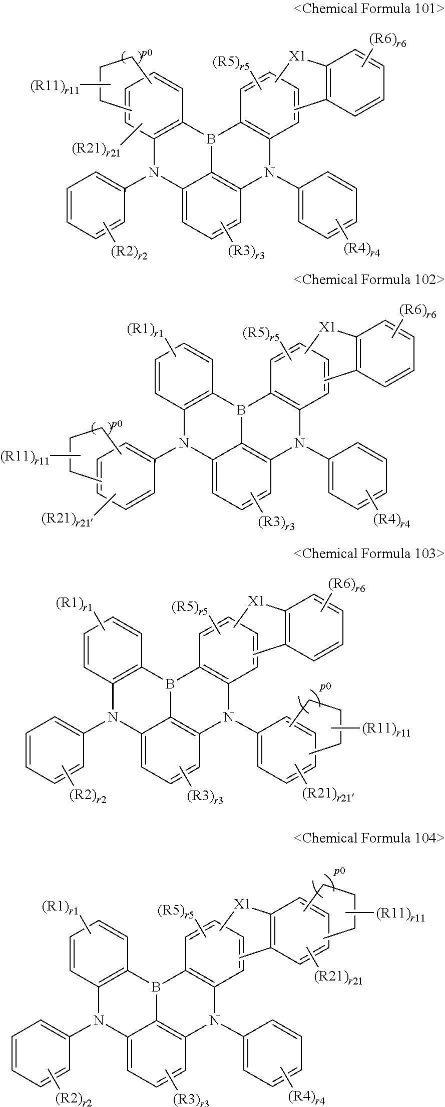

wherein in Chemical Formulae 101 to 104:

X1, R1 to R6 and r1 to r6 have the same definitions as in Chemical Formula 1;

p0 is 1 or 2;

R11 is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bonds to adjacent substituents to form a substituted or unsubstituted ring,

R21 is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group;

r11 is an integer of 0 to 8, r21 is an integer of 0 to 2, and r21′ is an integer of 0 to 3; and when r11 and r21′ are each 2 or greater or r21 is 2, the substituents in the parentheses are the same as or different from each other.

In one embodiment of the present specification, the descriptions on R1 to R6 provided above can be applied to R21 except for the descriptions on the forming of a ring.

In one embodiment of the present specification, R21 is hydrogen, deuterium, or a substituted or unsubstituted C1-C10 alkyl group.

In one embodiment of the present specification, R21 is hydrogen, deuterium, or a substituted or unsubstituted methyl group.

In one embodiment of the present specification, R21 is hydrogen or deuterium.

In one embodiment of the present specification, Chemical Formula 1 is any one of the following Chemical Formulae 201 to 215:

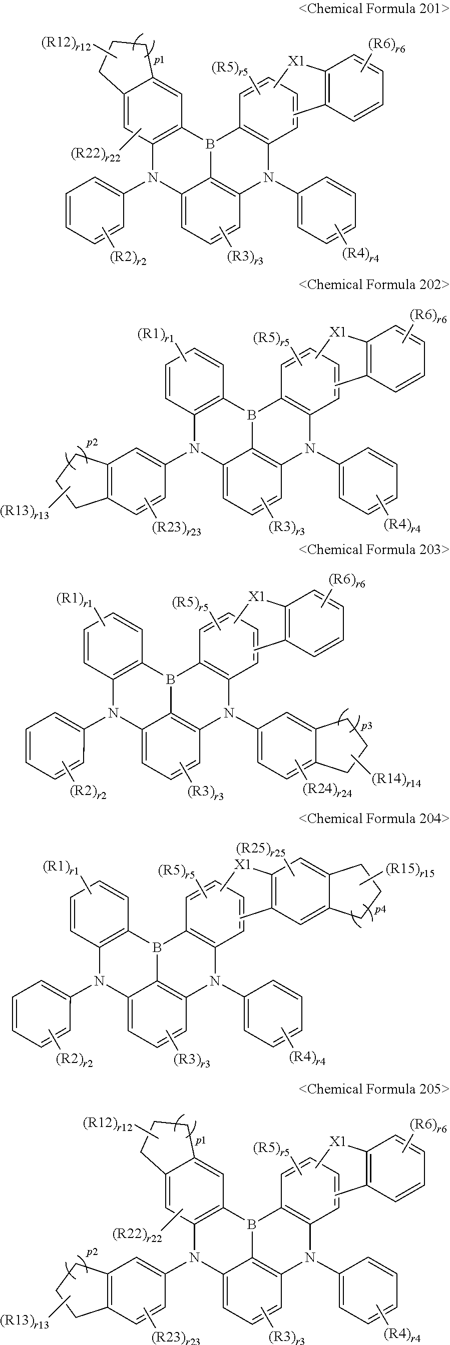

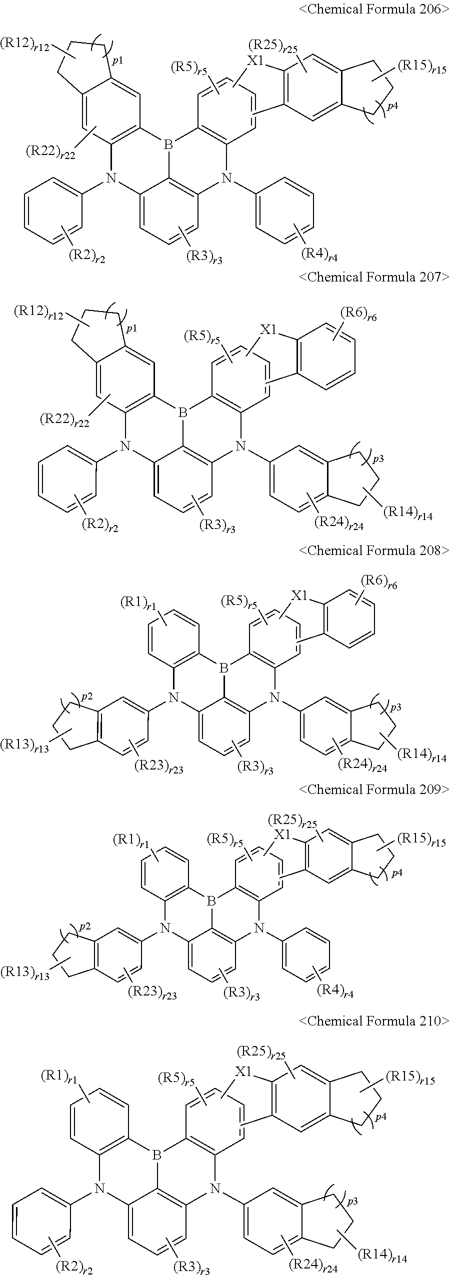

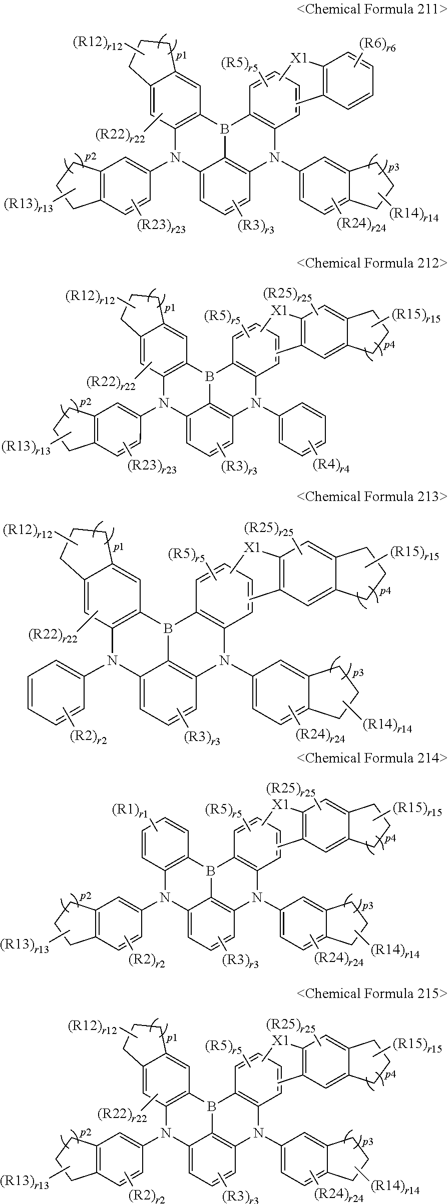

wherein in Chemical Formulae 201 to 215:

X1 and r1 to r6 have the same definitions as in Chemical Formula 1;

p1 to p4 are each 1 or 2;

R1 to R6 and R22 to R25 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group;

R12 to R15 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring;

r12 to r15 are each an integer of 0 to 8, r22 and r24 are each an integer of 0 to 2, and r23 and r25 are each an integer of 0 to 3; and when r12 to r15, r23 and r25 are each 2 or greater or r22 and r24 are 2, the substituents in the parentheses are the same as or different from each other.

In one embodiment of the present specification, p1 to p4 are the same as or different from each other.

In one embodiment of the present specification, the descriptions on R1 to R6 provided above can be applied to R22 to R25 except for the descriptions on the forming of a ring.

In one embodiment of the present specification, R22 to R25 are the same as or different from each other, and each independently is hydrogen, deuterium, or a substituted or unsubstituted C1-C10 alkyl group.

In one embodiment of the present specification, R22 to R25 are the same as or different from each other, and each independently is hydrogen, deuterium, or a substituted or unsubstituted C1-C6 alkyl group.

In one embodiment of the present specification, R22 and R24 are hydrogen or deuterium.

In one embodiment of the present specification, R23 and R25 are the same as or different from each other, and each independently is hydrogen, deuterium, or a substituted or unsubstituted methyl group.

In one embodiment of the present specification, the descriptions on R11 provided above can be applied to R12 to R15.

In one embodiment of the present specification, R12 to R15 are the same as or different from each other, and each independently is hydrogen, deuterium, or a substituted or unsubstituted C1-C10 alkyl group, or bond to adjacent substituents to form a substituted or unsubstituted C6-C30 aromatic hydrocarbon ring.

In one embodiment of the present specification, R12 to R15 are the same as or different from each other, and each independently is hydrogen, deuterium, or a substituted or unsubstituted C1-C6 alkyl group, or bond to adjacent substituents to form a substituted or unsubstituted C6-C20 aromatic hydrocarbon ring.

In one embodiment of the present specification, R12 to R15 are the same as or different from each other, and each independently is hydrogen, deuterium, or a substituted or unsubstituted methyl group, or bond to adjacent substituents to form a substituted or unsubstituted benzene ring.

R12 to R15 bonding to adjacent substituents to form an aromatic hydrocarbon ring refers to adjacent four R12s, adjacent four R13s, adjacent four R14s, or adjacent four R15s bonding to each other to form an aromatic hydrocarbon ring.

In one embodiment of the present specification, two or four of R12s are a methyl group that is unsubstituted or substituted with deuterium.

In one embodiment of the present specification, two or four of R13s are a methyl group that is unsubstituted or substituted with deuterium.

In one embodiment of the present specification, two or four of R14s are a methyl group that is unsubstituted or substituted with deuterium.

In one embodiment of the present specification, two or four of R15s are a methyl group that is unsubstituted or substituted with deuterium.

In one embodiment of the present specification, r12 is 2 or greater. In another embodiment, r12 is 2 or 4. In another embodiment, r12 is 8.

In one embodiment of the present specification, r13 is 2 or greater. In another embodiment, r13 is 2 or 4. In another embodiment, r13 is 8.

In one embodiment of the present specification, r14 is 2 or greater. In another embodiment, r14 is 2 or 4. In another embodiment, r14 is 8.

In one embodiment of the present specification, r15 is 2 or greater. In another embodiment, r15 is 2 or 4. In another embodiment, r15 is 8.

In one embodiment of the present specification,

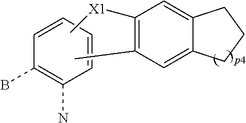

of Chemical Formulae 204, 206, 209, 210 and 212 to 215 are selected from among the following structures:

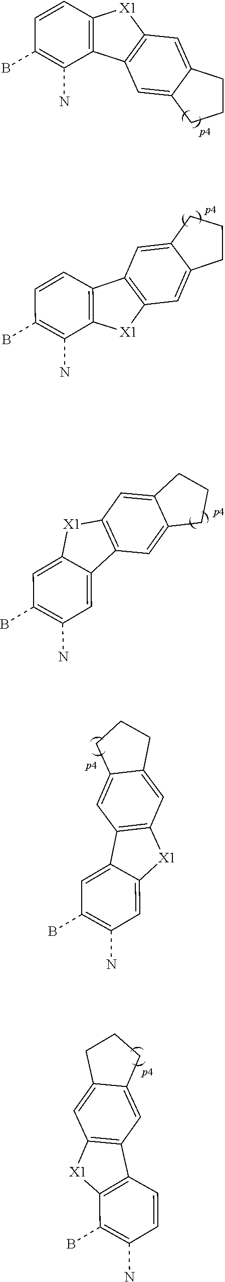

wherein in the structures, a dotted line is a site fused to Chemical Formula 1.

In one embodiment of the present specification, R7 and R8 are the same as or different from each other, and each independently is hydrogen, deuterium, a substituted or unsubstituted C1-C10 alkyl group, or a substituted or unsubstituted C6-C30 aryl group.

In one embodiment of the present specification, R7 and R8 are the same as or different from each other, and each independently is hydrogen, deuterium, a substituted or unsubstituted C1-C6 alkyl group, or a substituted or unsubstituted C6-C20 aryl group.

In one embodiment of the present specification, R7 and R8 are the same as or different from each other, and each independently is hydrogen, deuterium, a substituted or unsubstituted methyl group, or a substituted or unsubstituted phenyl group.

In one embodiment of the present specification, R7 and R8 are the same as or different from each other, and each independently is hydrogen, deuterium, a methyl group that is unsubstituted or substituted with deuterium, or a phenyl group that is unsubstituted or substituted with deuterium.

In one embodiment of the present specification, R7 and R8 are a methyl group.

In one embodiment of the present specification, r1 is an integer of 0 to 4, and when r1 is 2 or greater, the R1s are the same as or different from each other.

In one embodiment of the present specification, r2 is an integer of 0 to 5, and when r2 is 2 or greater, the R2s are the same as or different from each other.

In one embodiment of the present specification, r3 is an integer of 0 to 3, and when r3 is 2 or greater, the R3s are the same as or different from each other.

In one embodiment of the present specification, r4 is an integer of 0 to 5, and when r4 is 2 or greater, the R4s are the same as or different from each other.

In one embodiment of the present specification, r5 is an integer of 0 to 2, and when r5 is 2, the R5s are the same as or different from each other.

In one embodiment of the present specification, r6 is an integer of 0 to 4, and when r6 is 2 or greater, the R6s are the same as or different from each other.

In one embodiment of the present specification, the compound of Chemical Formula 1 is one compound selected from among the following compounds:

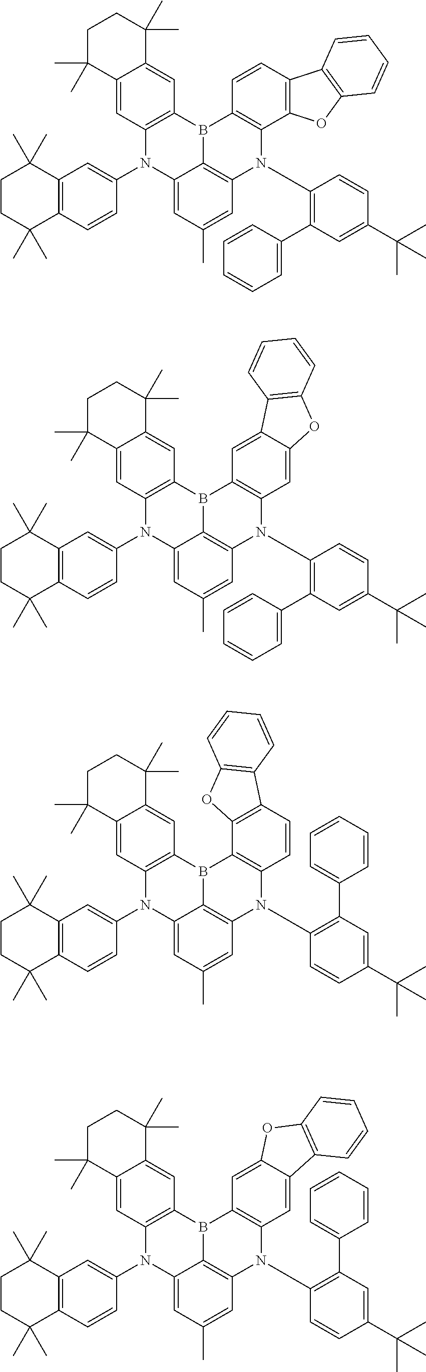 [SMILES: Cc1cc2c3c(c1)N(c1ccc(C(C)(C)C)cc1-c1ccccc1)c1c(ccc4c1oc1ccccc14)B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1ccccc14]

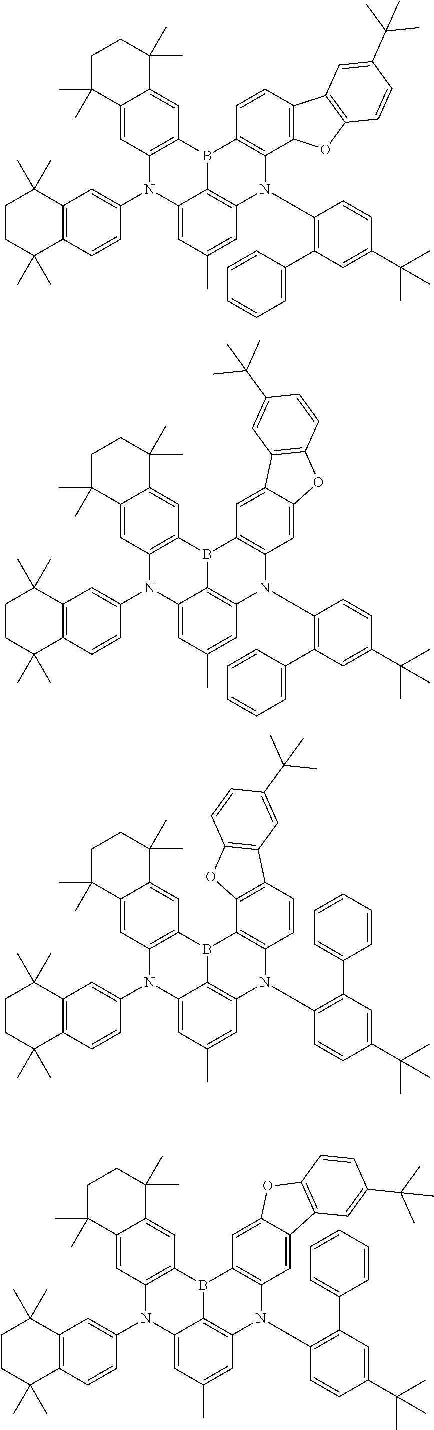

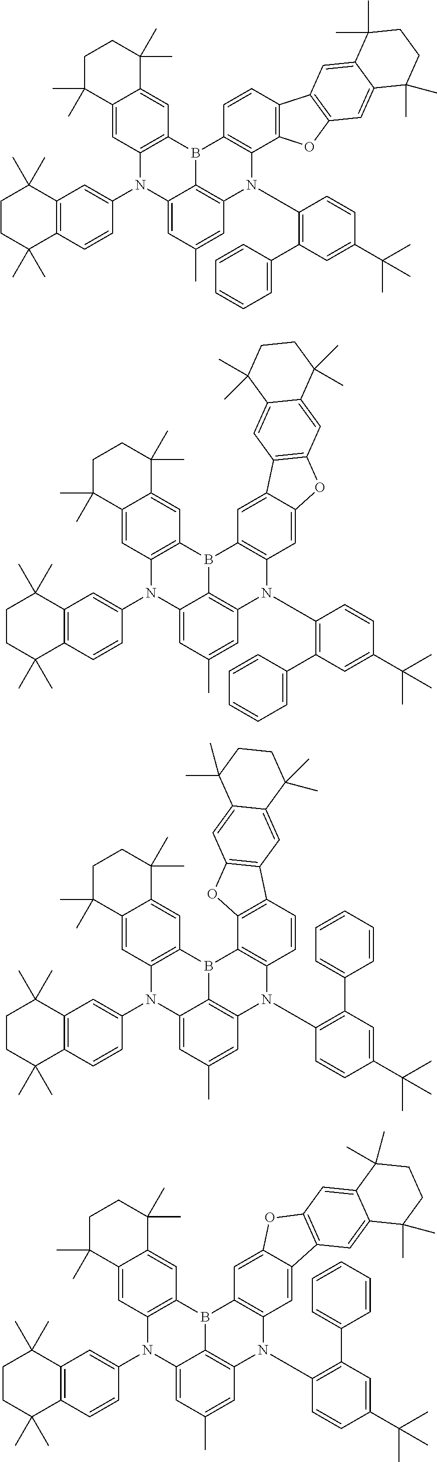

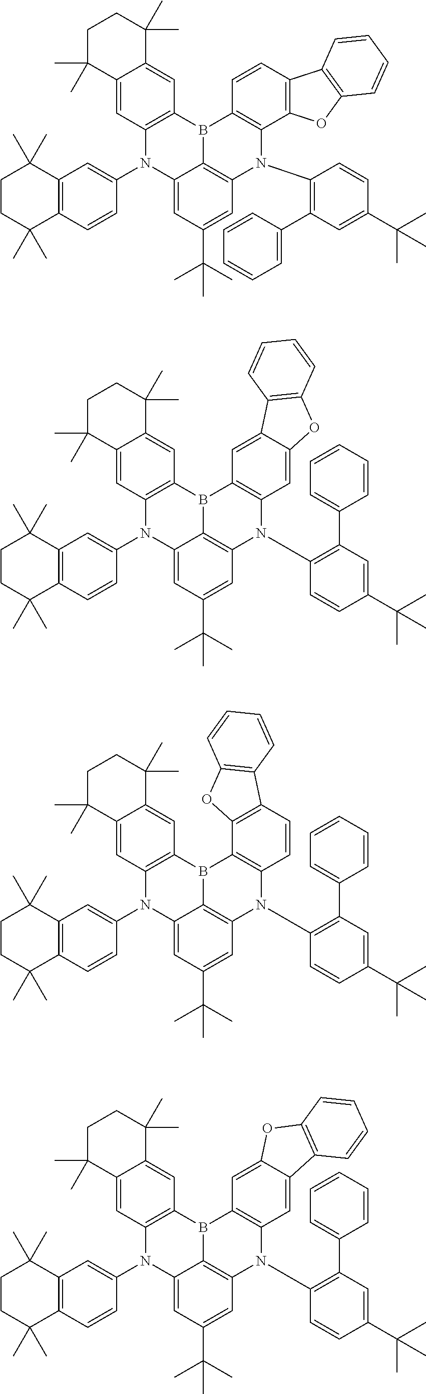

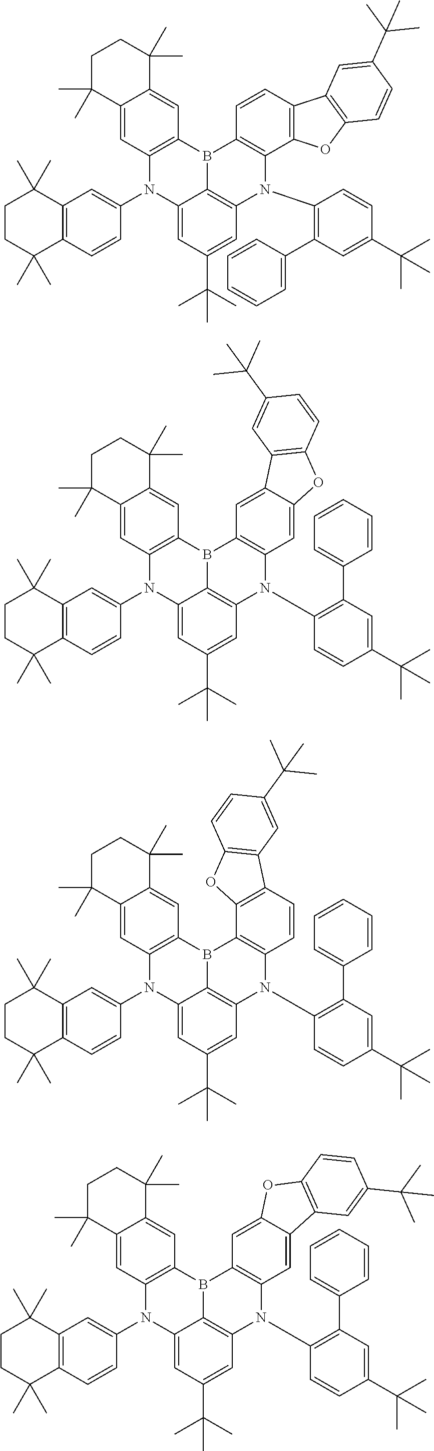

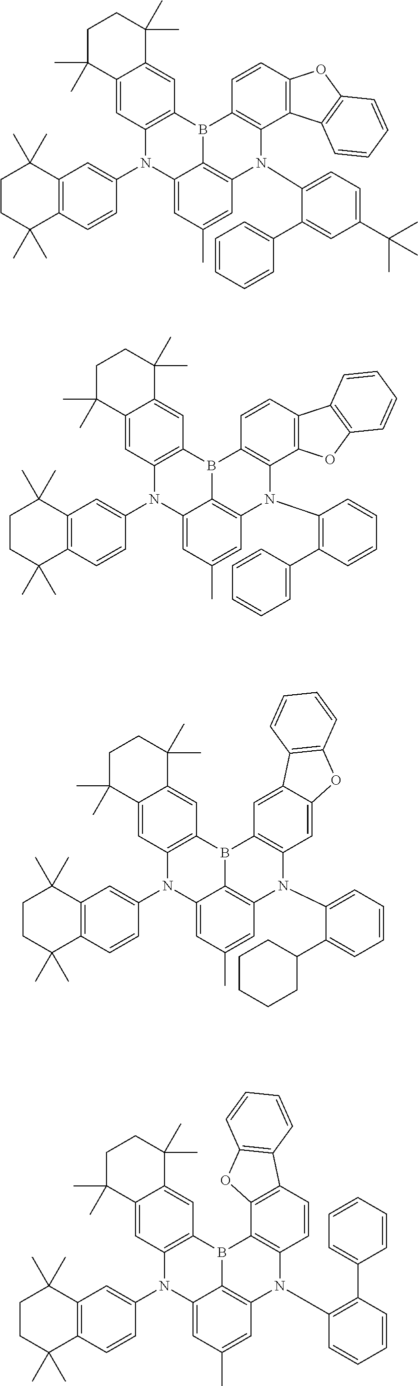 [SMILES: Cc1cc2c3c(c1)N(c1ccc(C(C)(C)C)cc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1cc2c3c(c1)N(c1ccccc1-c1ccccc1)c1c(ccc4c1oc1ccccc14)B3c1cc3c(cc1N2c1ccc2c(c1)C(C)(C)CCC2(C)C)C(C)(C)CCC3(C)C ; Cc1cc2c3c(c1)N(c1ccccc1C1CCCCC1)c1cc4oc5ccccc5c4cc1B3c1cc3c(cc1N2c1ccc2c(c1)C(C)(C)CCC2(C)C)C(C)(C)CCC3(C)C ; Cc1cc2c3c(c1)N(c1ccccc1-c1ccccc1)c1ccc4c(oc5ccccc54)c1B3c1cc3c(cc1N2c1ccc2c(c1)C(C)(C)CCC2(C)C)C(C)(C)CCC3(C)C]

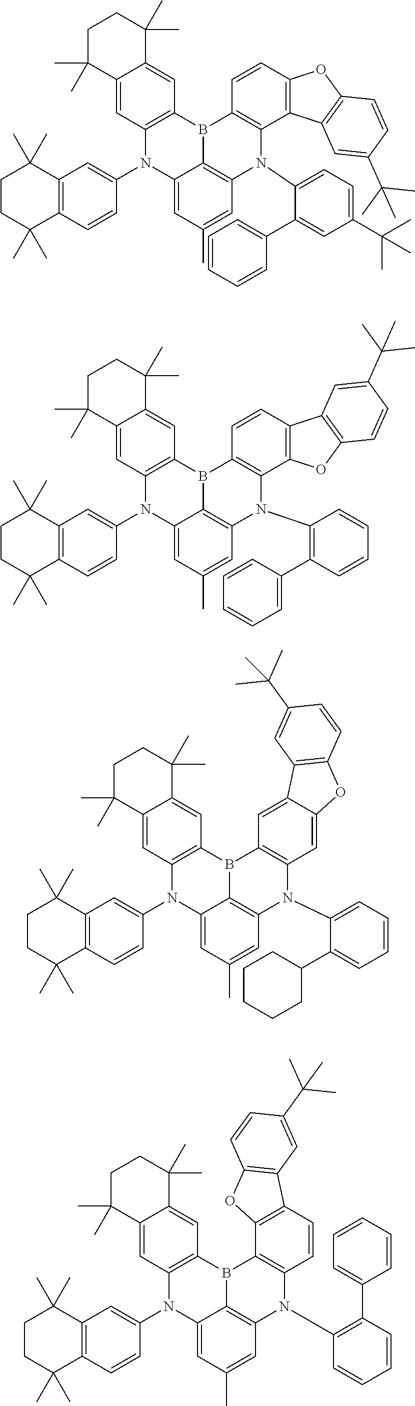

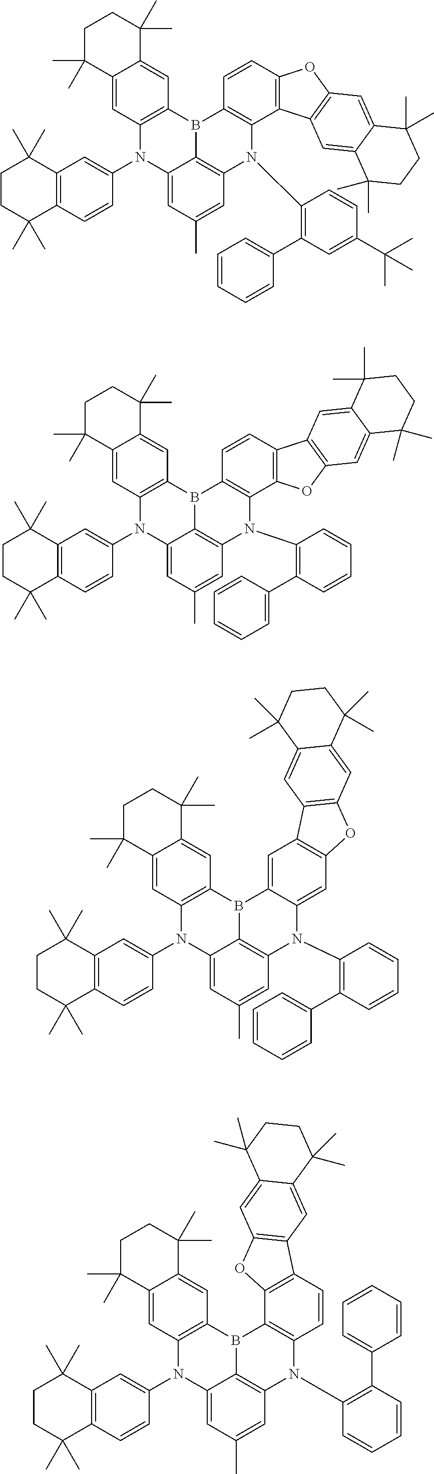

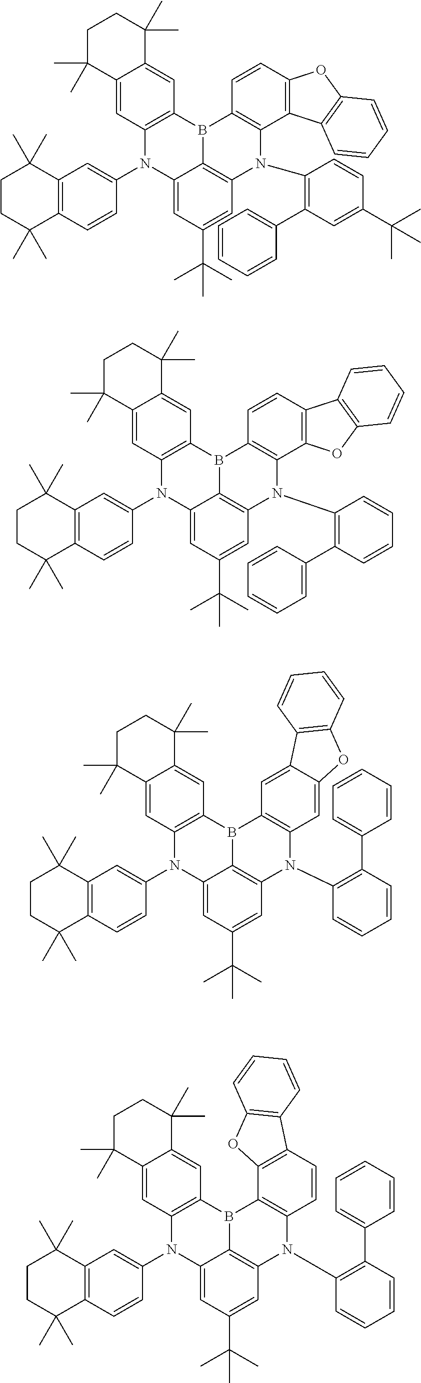

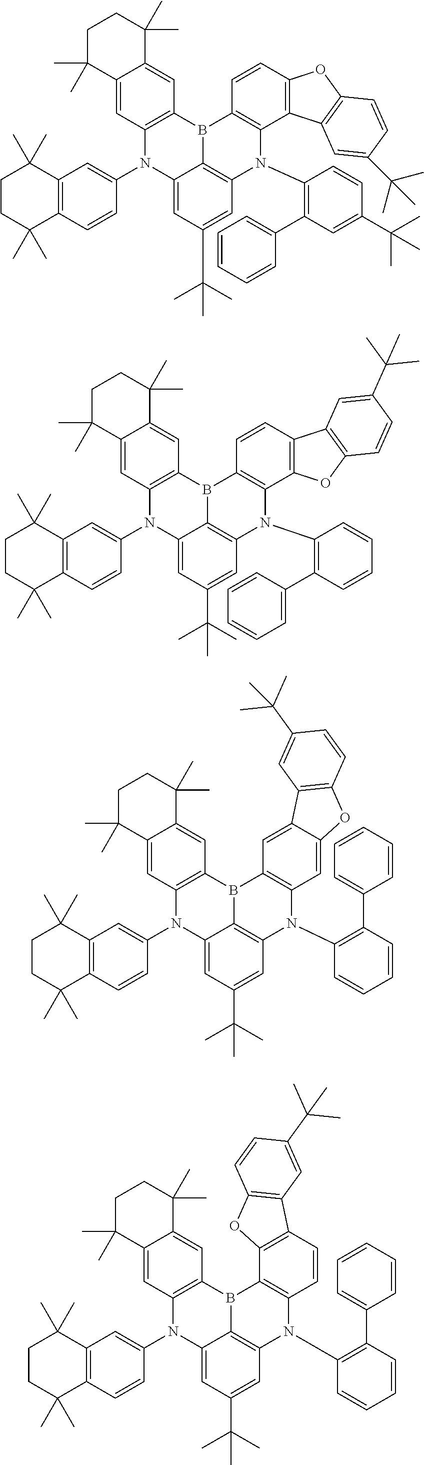

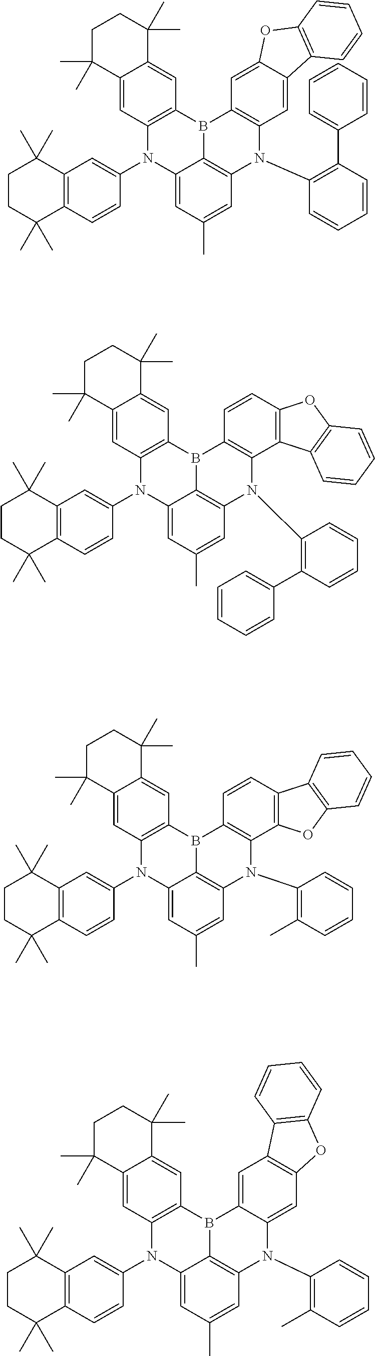 [SMILES: Cc1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccccc14 ; Cc1cc2c3c(c1)N(c1ccccc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1cc2c3c(c1)N(c1ccccc1C)c1c(ccc4c1oc1ccccc14)B3c1cc3c(cc1N2c1ccc2c(c1)C(C)(C)CCC2(C)C)C(C)(C)CCC3(C)C ; Cc1cc2c3c(c1)N(c1ccccc1C)c1cc4oc5ccccc5c4cc1B3c1cc3c(cc1N2c1ccc2c(c1)C(C)(C)CCC2(C)C)C(C)(C)CCC3(C)C]

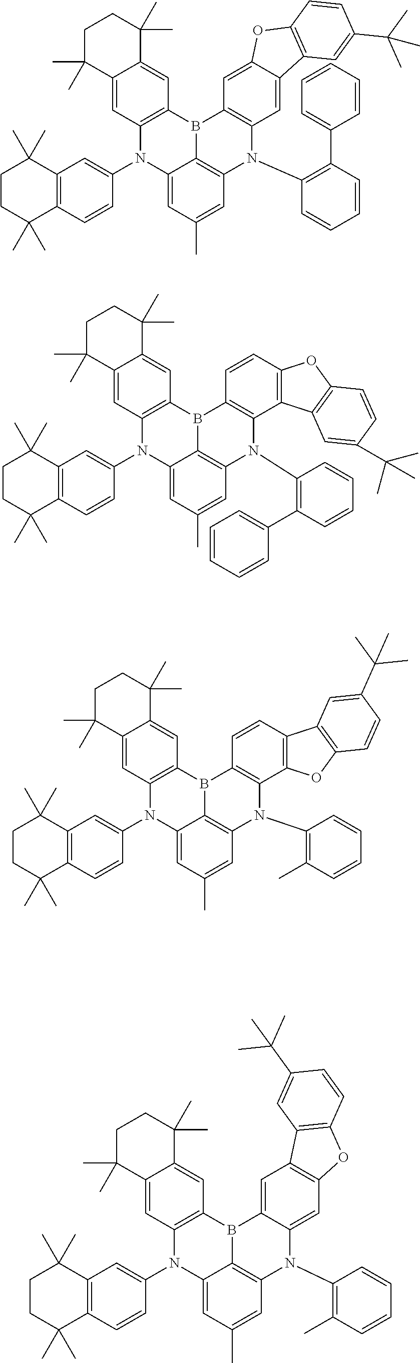 [SMILES: Cc1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1cc2c3c(c1)N(c1ccccc1C)c1c(ccc4c1oc1ccc(C(C)(C)C)cc14)B3c1cc3c(cc1N2c1ccc2c(c1)C(C)(C)CCC2(C)C)C(C)(C)CCC3(C)C ; Cc1cc2c3c(c1)N(c1ccccc1C)c1cc4oc5ccc(C(C)(C)C)cc5c4cc1B3c1cc3c(cc1N2c1ccc2c(c1)C(C)(C)CCC2(C)C)C(C)(C)CCC3(C)C]

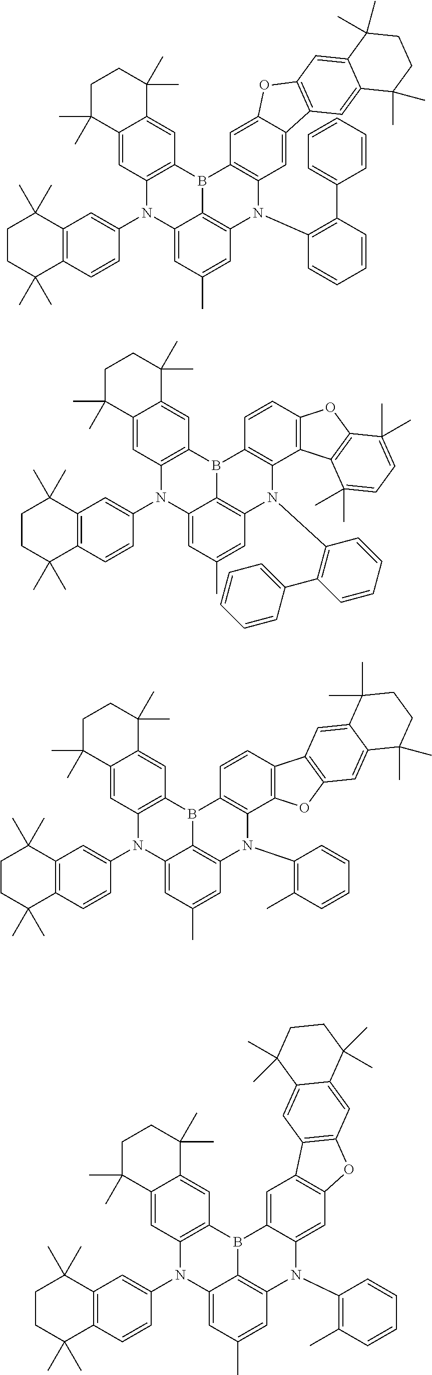

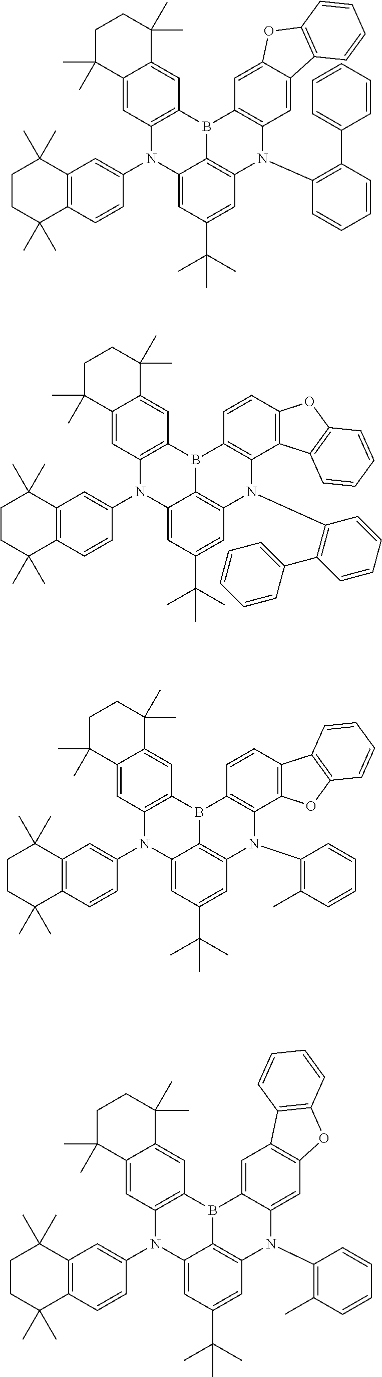 [SMILES: CC(C)(C)c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccccc14 ; CC(C)(C)c1cc2c3c(c1)N(c1ccccc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3c(oc4ccccc43)c21 ; Cc1ccccc1N1c2cc3oc4ccccc4c3cc2B2c3cc4c(cc3N(c3ccc5c(c3)C(C)(C)CCC5(C)C)c3cc(C(C)(C)C)cc1c32)C(C)(C)CCC4(C)C]

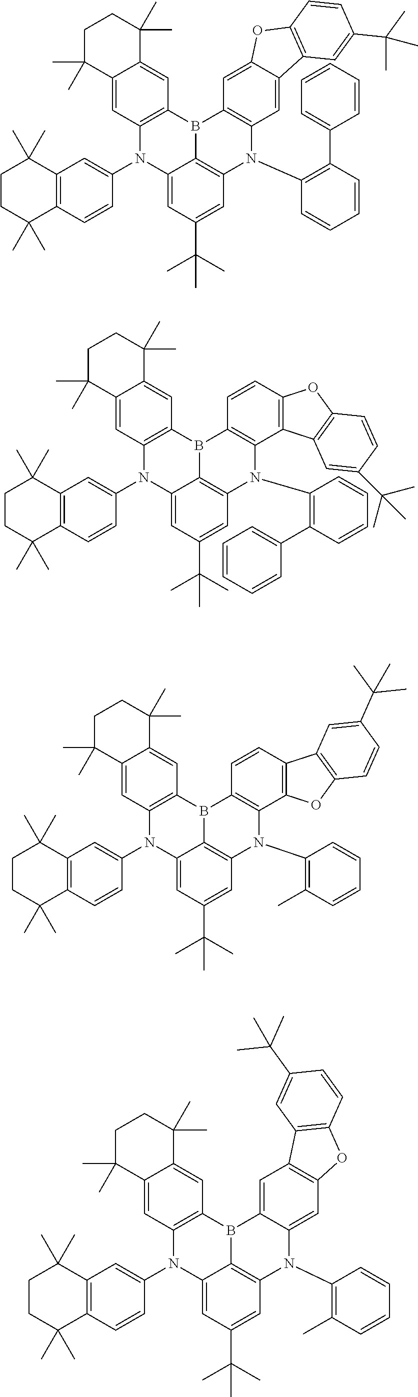 [SMILES: CC(C)(C)c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; CC(C)(C)c1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)CCC5(C)C)c3cc(C(C)(C)C)cc1c32)C(C)(C)CCC4(C)C]

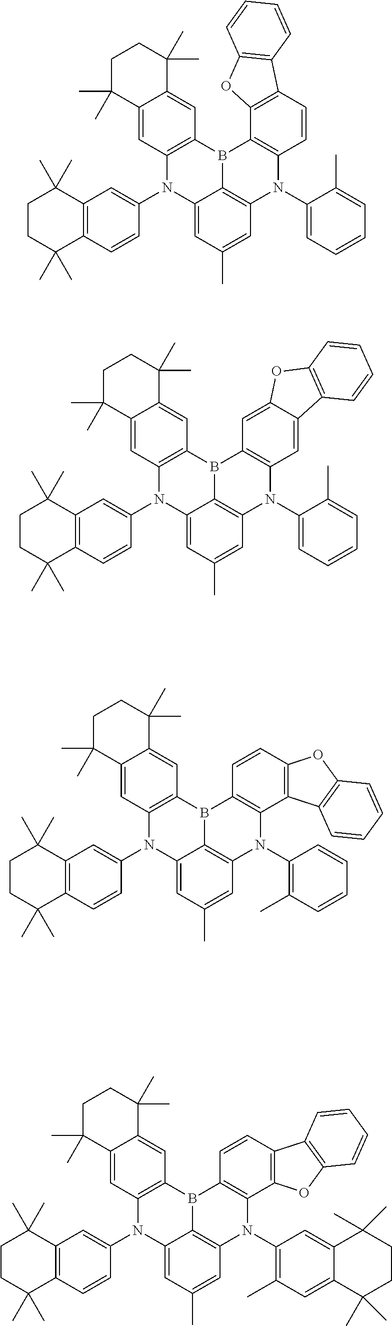 [SMILES: Cc1cc2c3c(c1)N(c1ccccc1C)c1ccc4c(oc5ccccc54)c1B3c1cc3c(cc1N2c1ccc2c(c1)C(C)(C)CCC2(C)C)C(C)(C)CCC3(C)C ; Cc1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1ccccc14 ; Cc1cc2c3c(c1)N(c1ccccc1C)c1c(ccc4oc5ccccc5c14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1c(ccc4c1oc1ccccc14)B3c1cc3c(cc1N2c1ccc2c(c1)C(C)(C)CCC2(C)C)C(C)(C)CCC3(C)C]

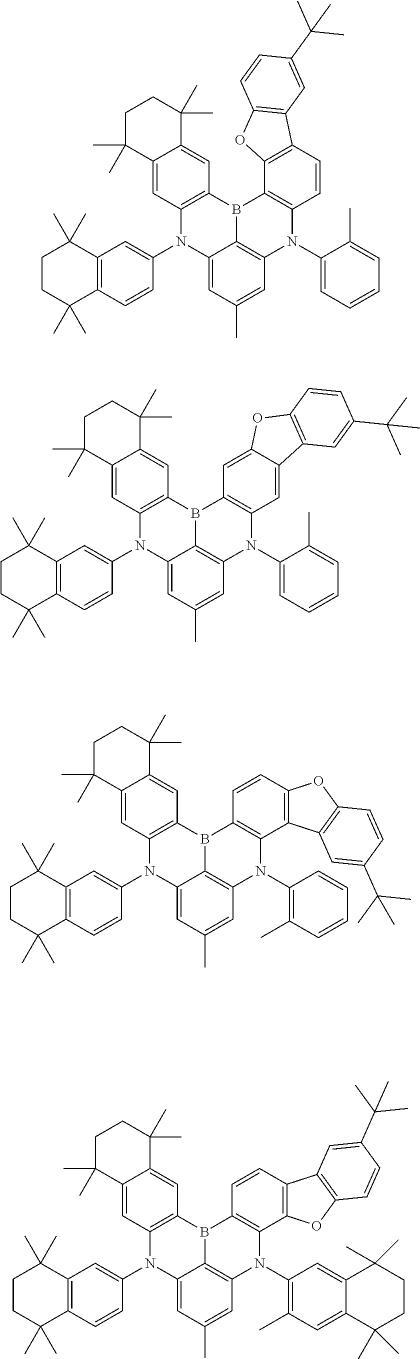 [SMILES: Cc1cc2c3c(c1)N(c1ccccc1C)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1cc2c3c(c1)N(c1ccccc1C)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1c(ccc4c1oc1ccc(C(C)(C)C)cc14)B3c1cc3c(cc1N2c1ccc2c(c1)C(C)(C)CCC2(C)C)C(C)(C)CCC3(C)C]

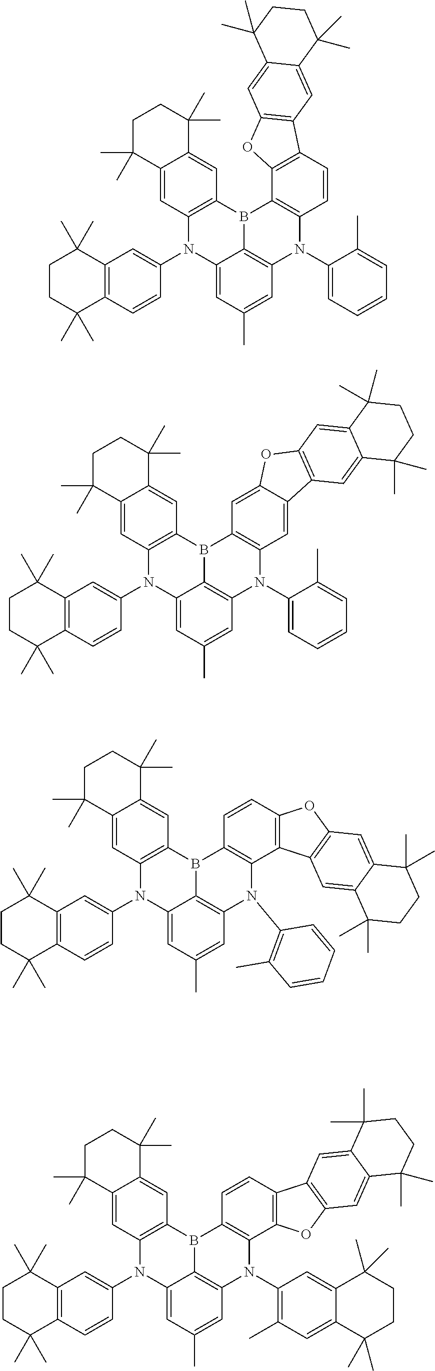

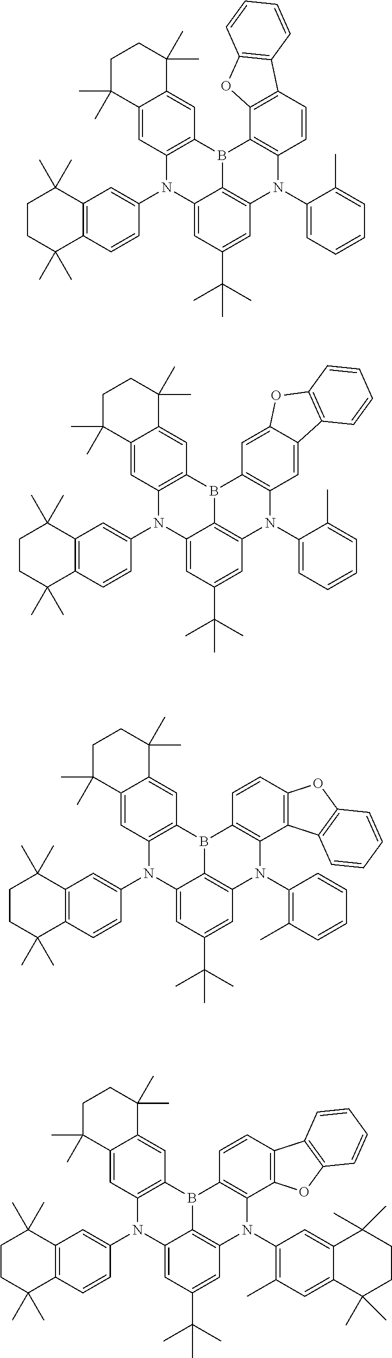 [SMILES: Cc1ccccc1N1c2cc(C(C)(C)C)cc3c2B(c2cc4c(cc2N3c2ccc3c(c2)C(C)(C)CCC3(C)C)C(C)(C)CCC4(C)C)c2c1ccc1c2oc2ccccc21 ; Cc1ccccc1N1c2cc3c(cc2B2c4cc5c(cc4N(c4ccc6c(c4)C(C)(C)CCC6(C)C)c4cc(C(C)(C)C)cc1c42)C(C)(C)CCC5(C)C)oc1ccccc13 ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3oc4ccccc4c3c21 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5ccccc54)c31)C(C)(C)CCC2(C)C]

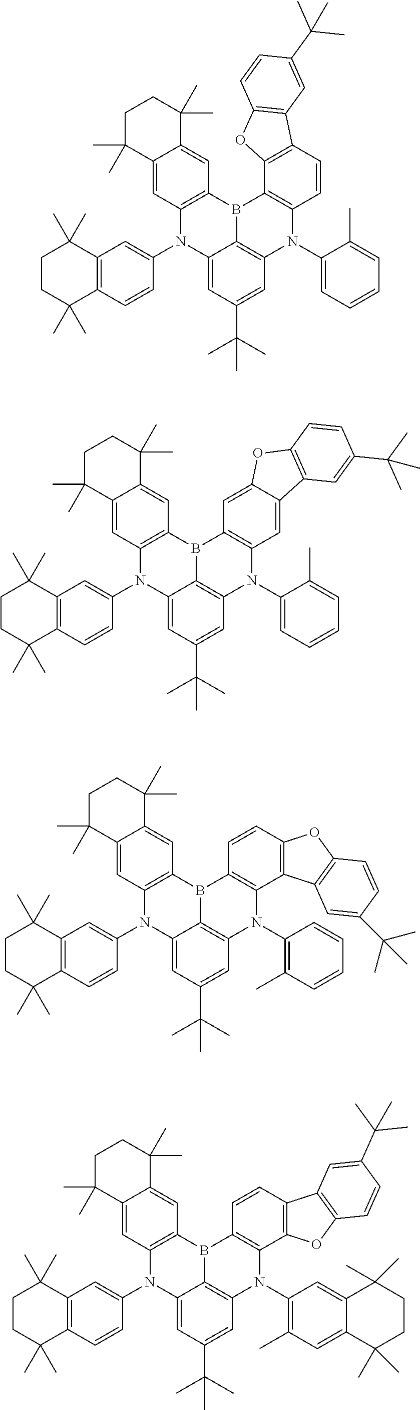 [SMILES: Cc1ccccc1N1c2cc(C(C)(C)C)cc3c2B(c2cc4c(cc2N3c2ccc3c(c2)C(C)(C)CCC3(C)C)C(C)(C)CCC4(C)C)c2c1ccc1c2oc2ccc(C(C)(C)C)cc21 ; Cc1ccccc1N1c2cc3c(cc2B2c4cc5c(cc4N(c4ccc6c(c4)C(C)(C)CCC6(C)C)c4cc(C(C)(C)C)cc1c42)C(C)(C)CCC5(C)C)oc1ccc(C(C)(C)C)cc13 ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C]

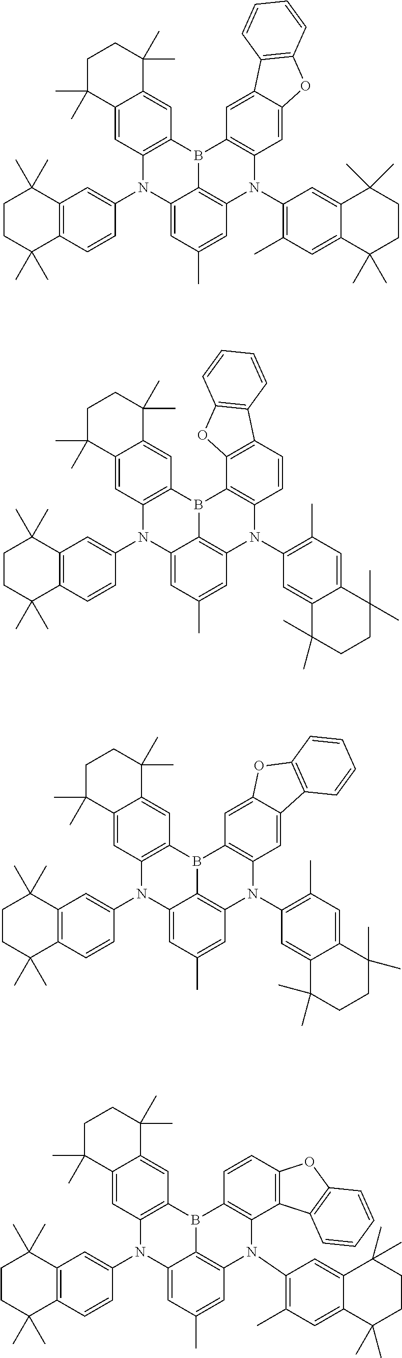 [SMILES: Cc1cc2c3c(c1)N(c1cc4c(cc1C)C(C)(C)CCC4(C)C)c1cc4oc5ccccc5c4cc1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1ccc4c(oc5ccccc54)c1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1ccccc14 ; Cc1cc2c3c(c1)N(c1cc4c(cc1C)C(C)(C)CCC4(C)C)c1c(ccc4oc5ccccc5c14)B3c1cc3c(cc1N2c1ccc2c(c1)C(C)(C)CCC2(C)C)C(C)(C)CCC3(C)C]

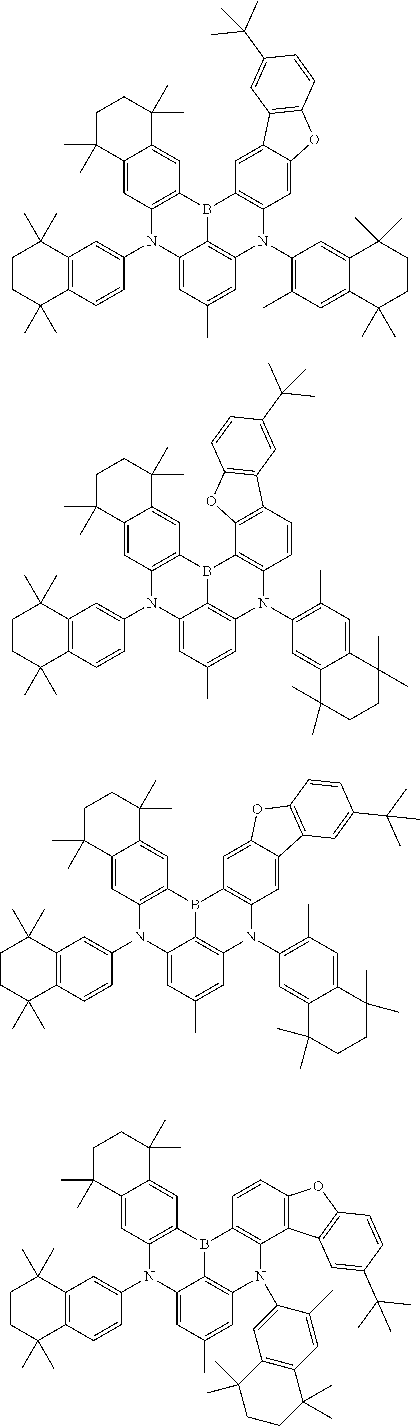

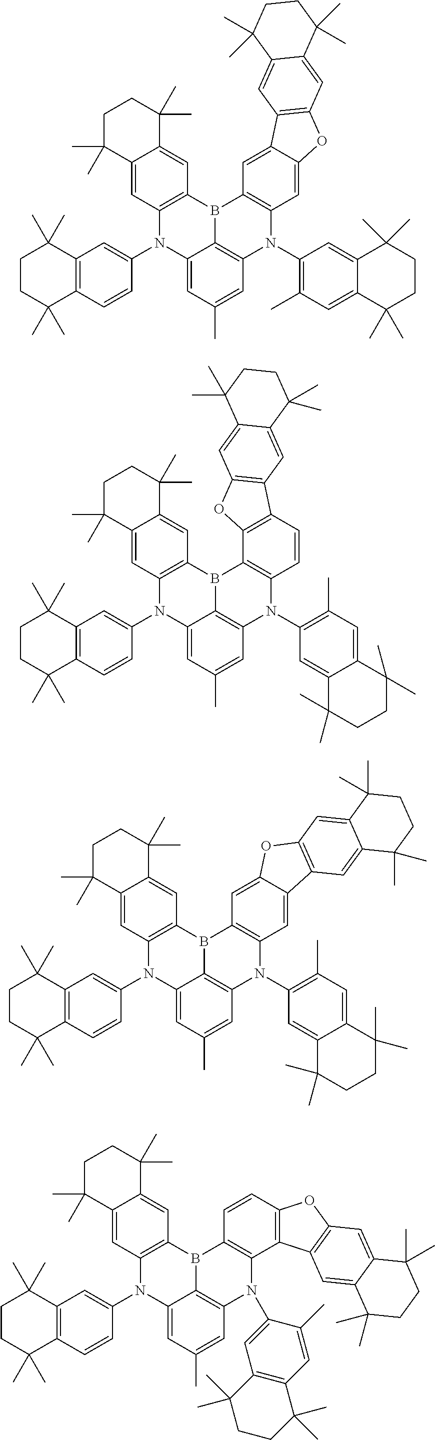

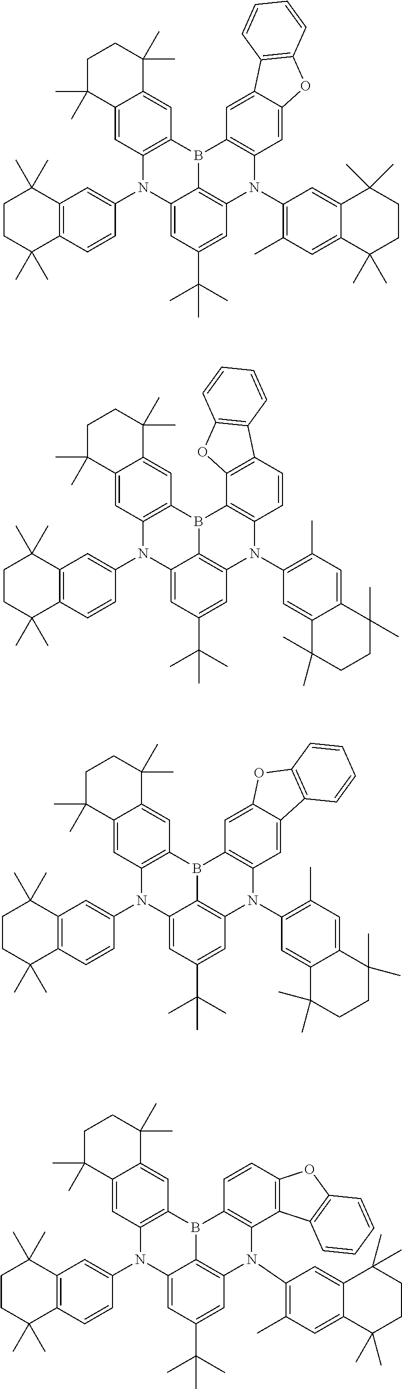

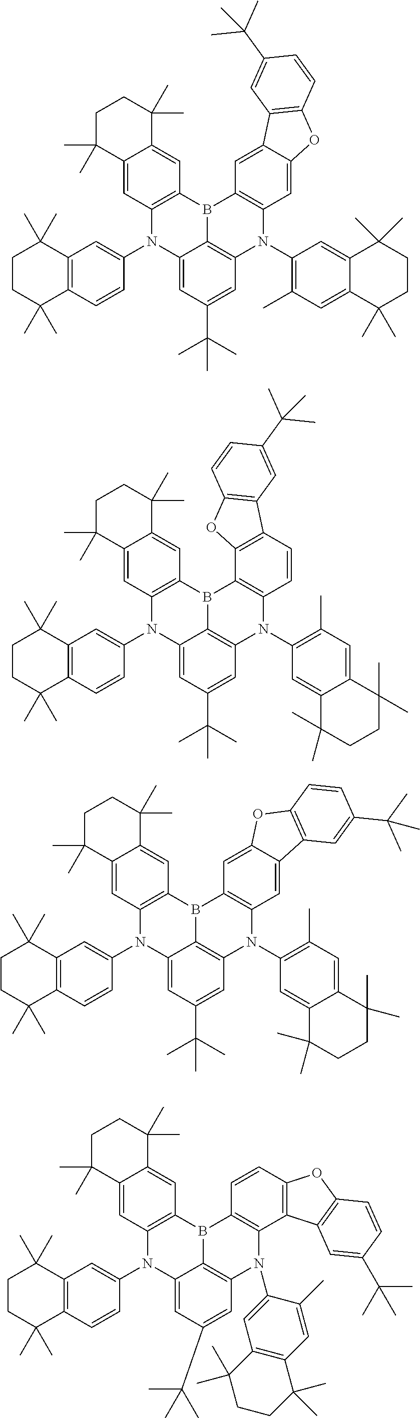

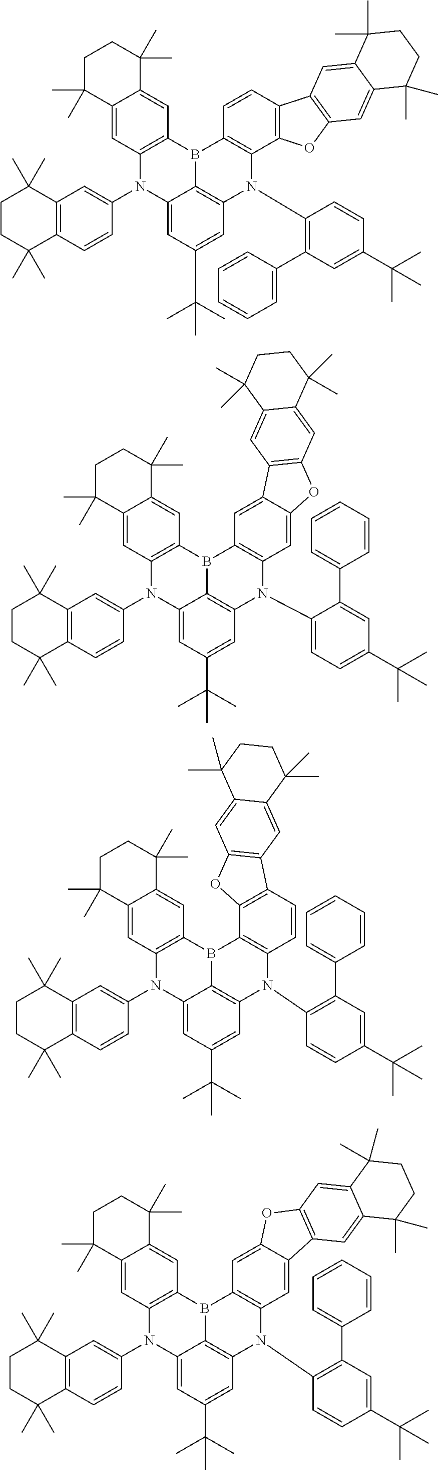

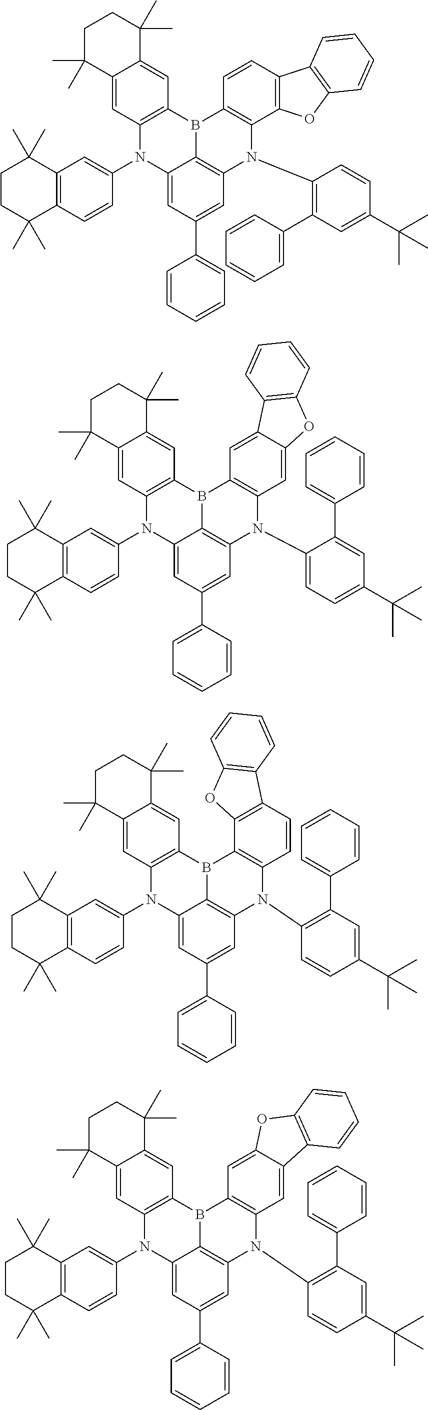

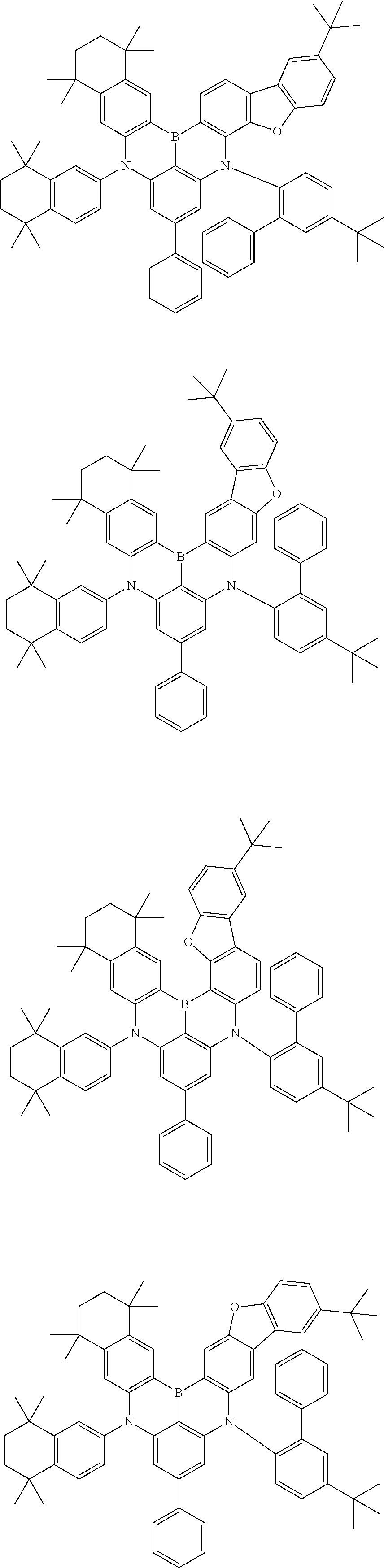

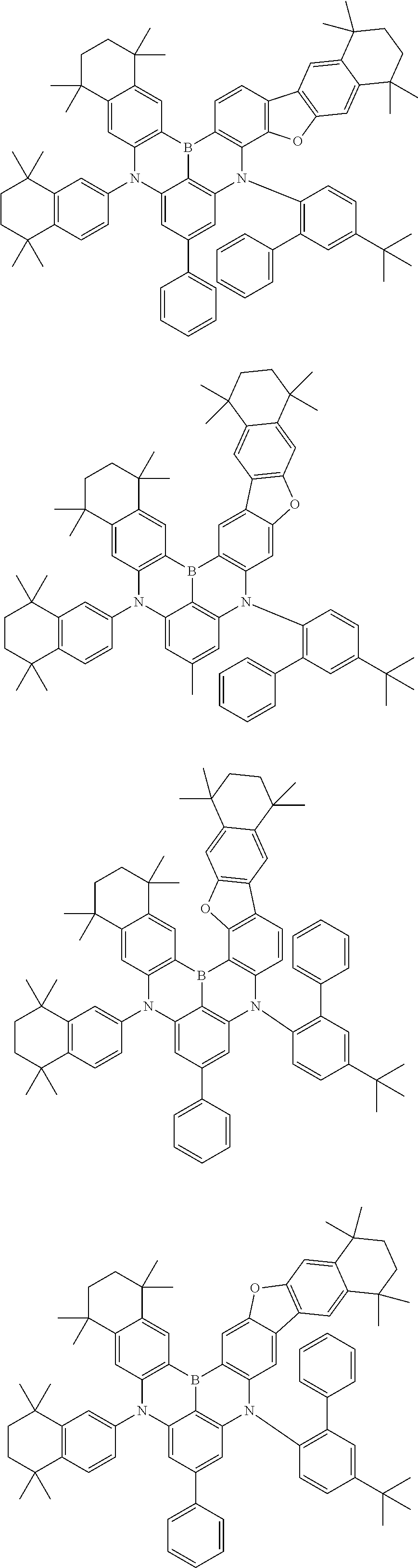

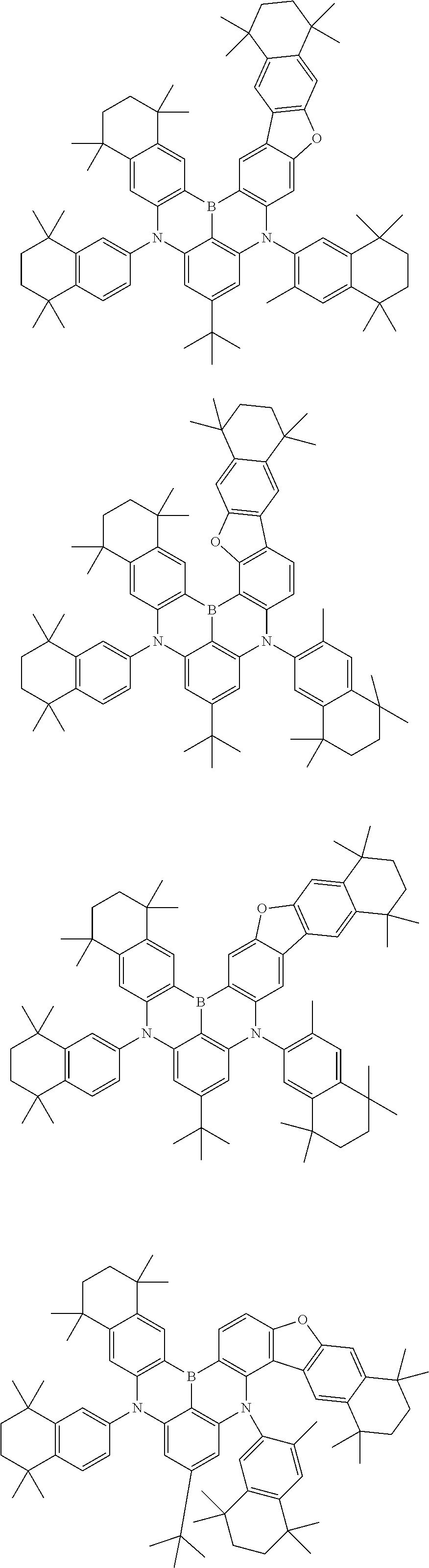

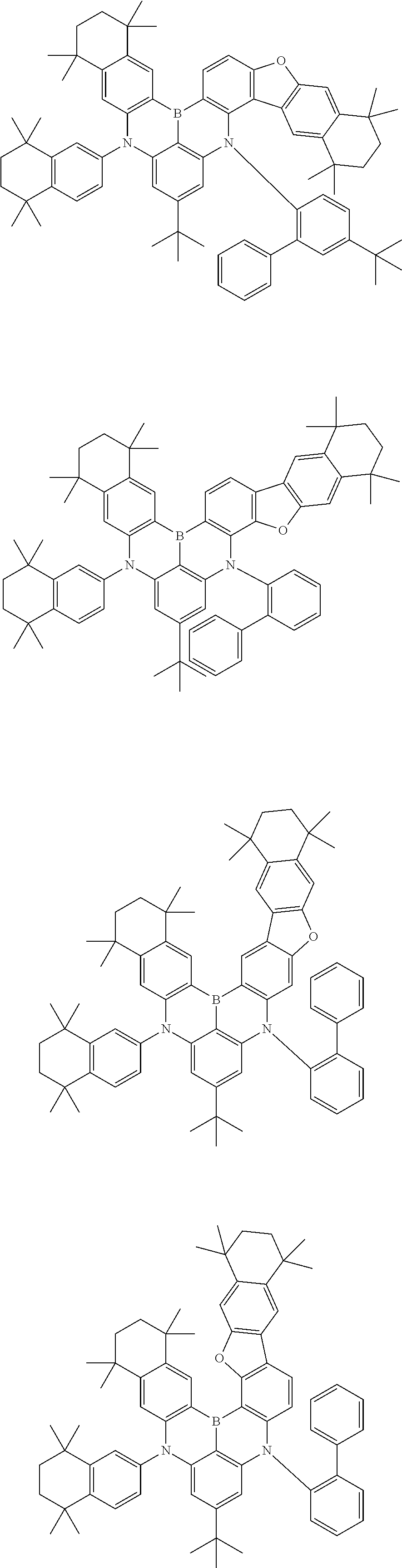

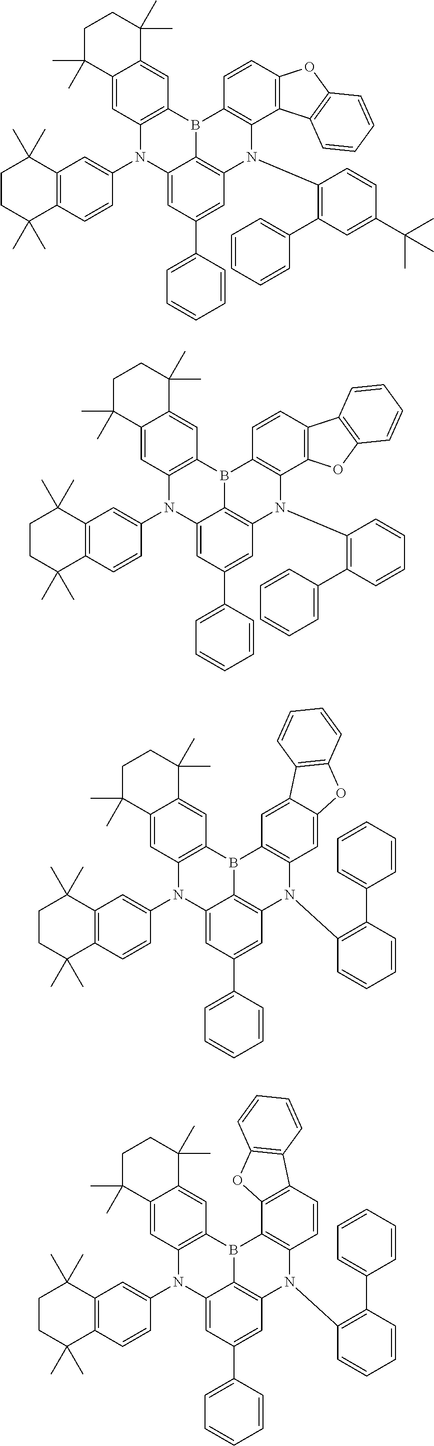

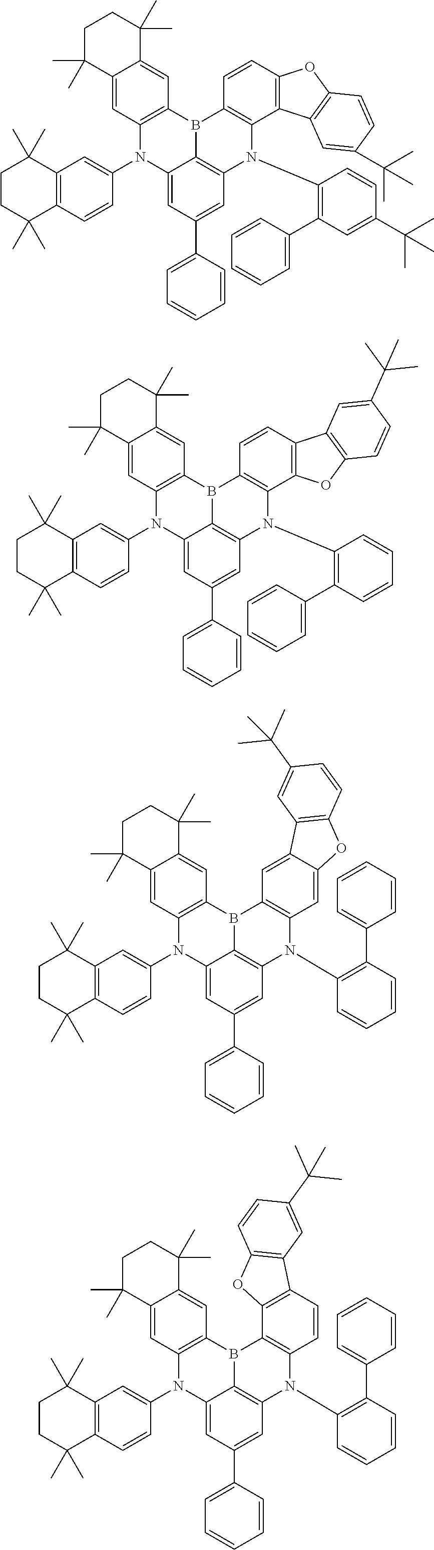

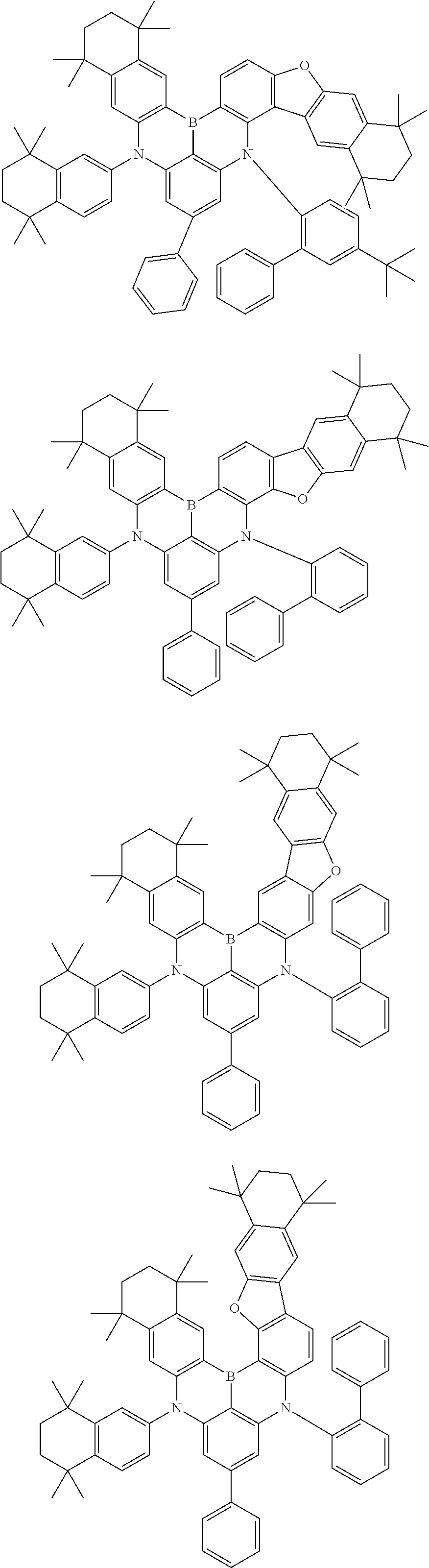

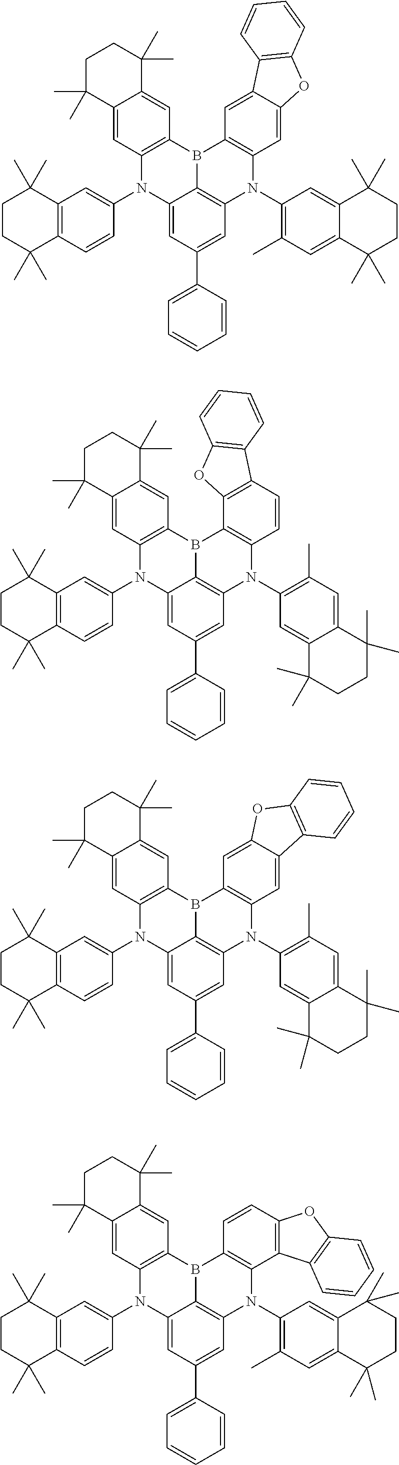

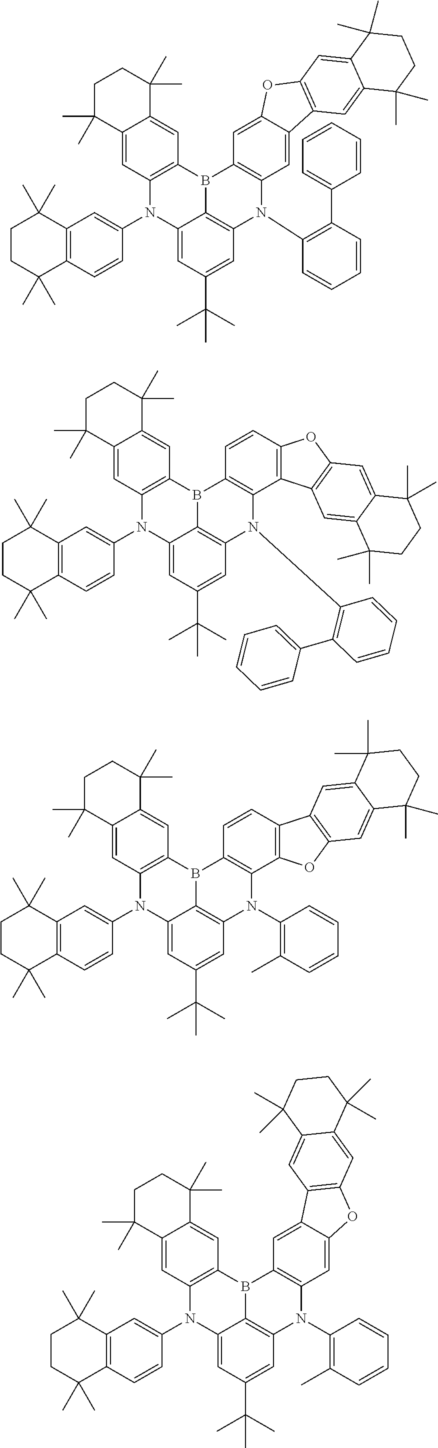

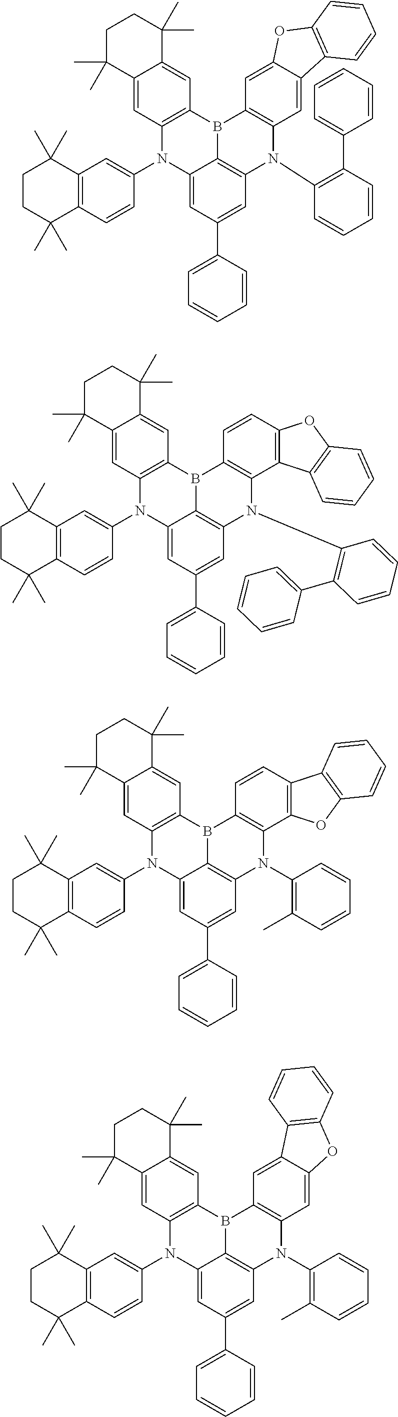

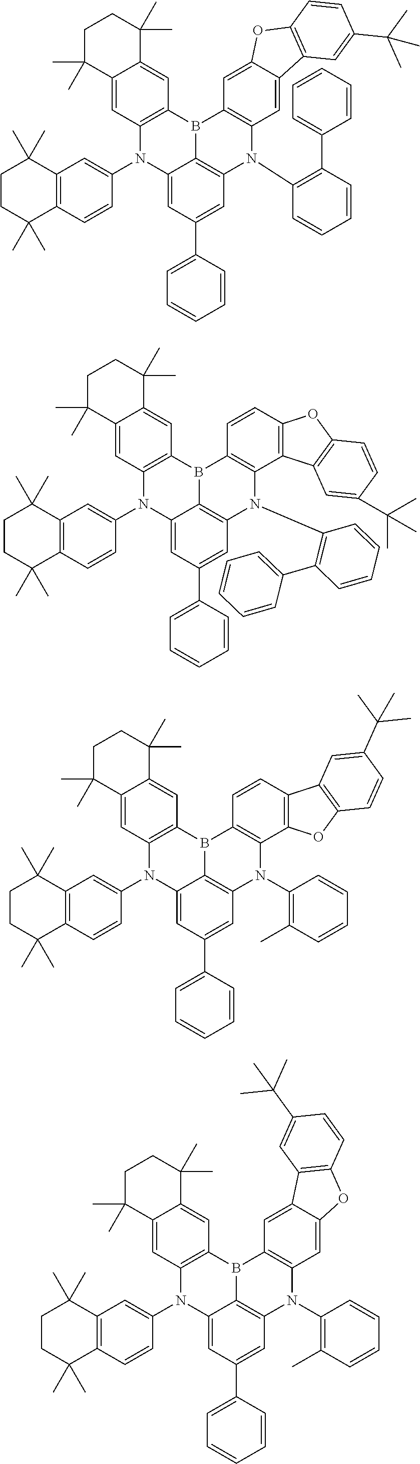

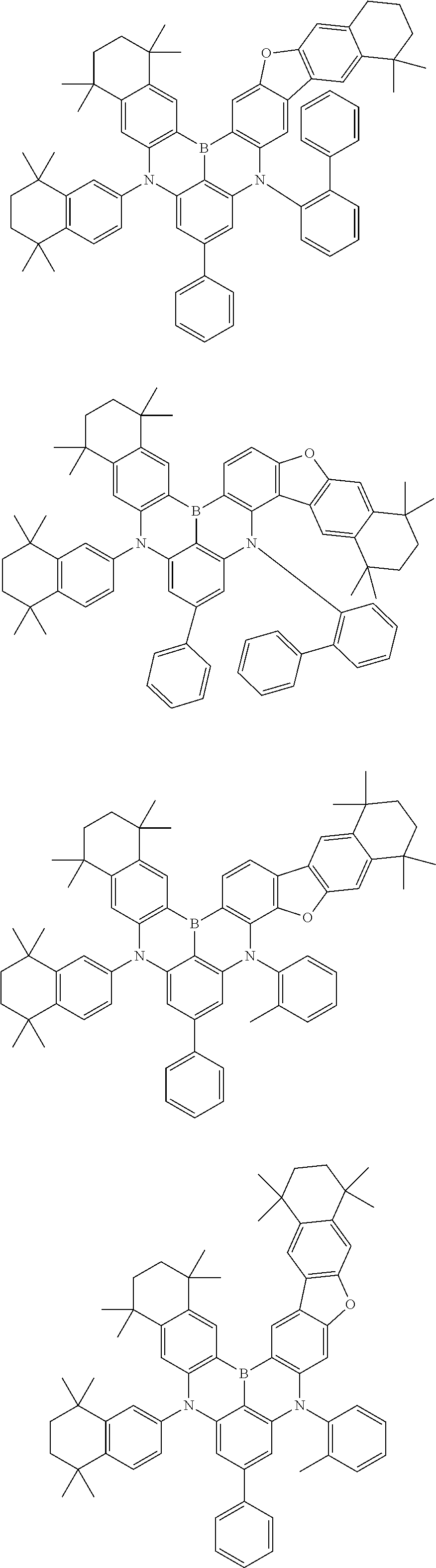

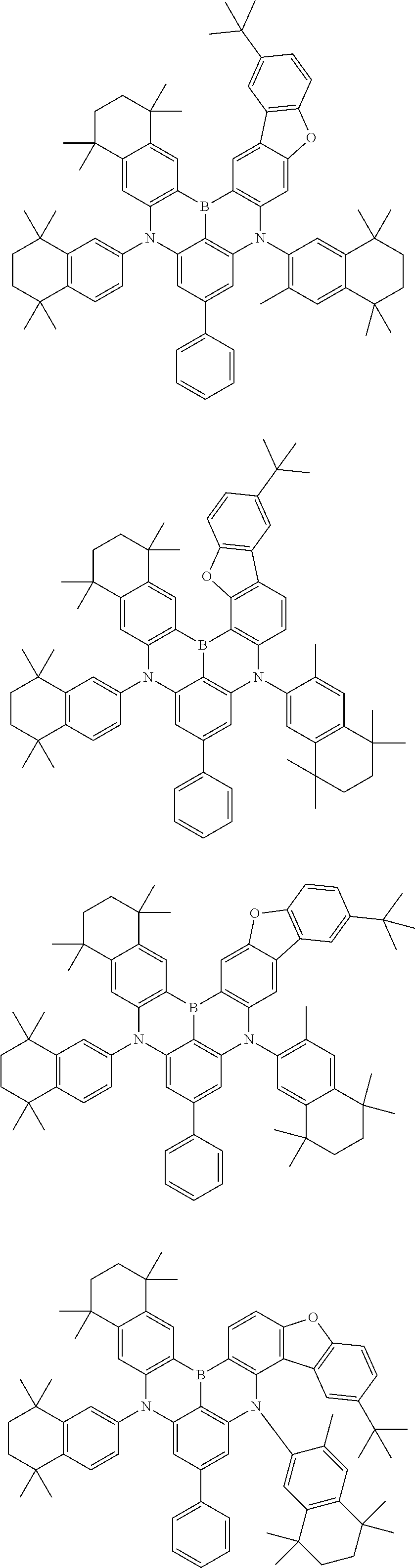

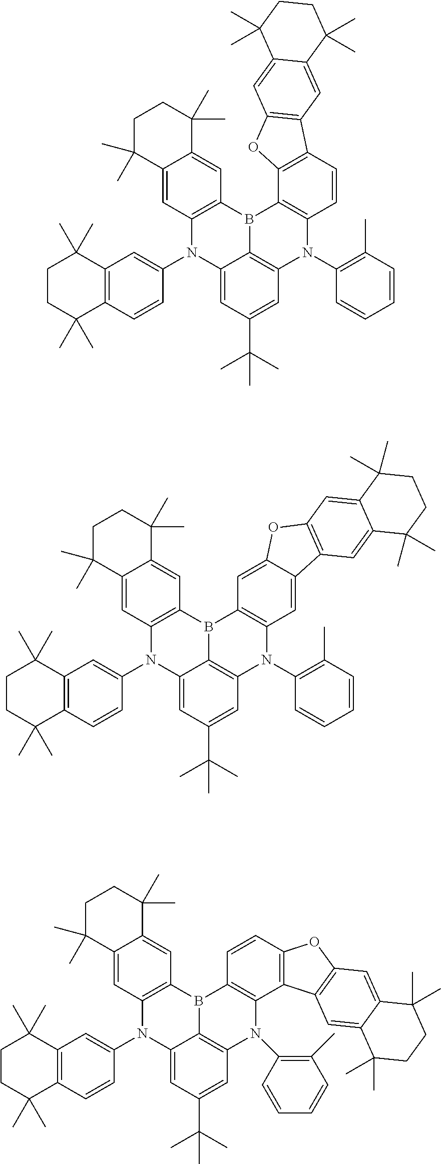 [SMILES: Cc1ccccc1N1c2cc(C(C)(C)C)cc3c2B(c2cc4c(cc2N3c2ccc3c(c2)C(C)(C)CCC3(C)C)C(C)(C)CCC4(C)C)c2c1ccc1c2oc2cc3c(cc21)C(C)(C)CCC3(C)C ; Cc1ccccc1N1c2cc3c(cc2B2c4cc5c(cc4N(c4ccc6c(c4)C(C)(C)CCC6(C)C)c4cc(C(C)(C)C)cc1c42)C(C)(C)CCC5(C)C)oc1cc2c(cc13)C(C)(C)CCC2(C)C ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3oc4cc5c(cc4c3c21)C(C)(C)CCC5(C)C]

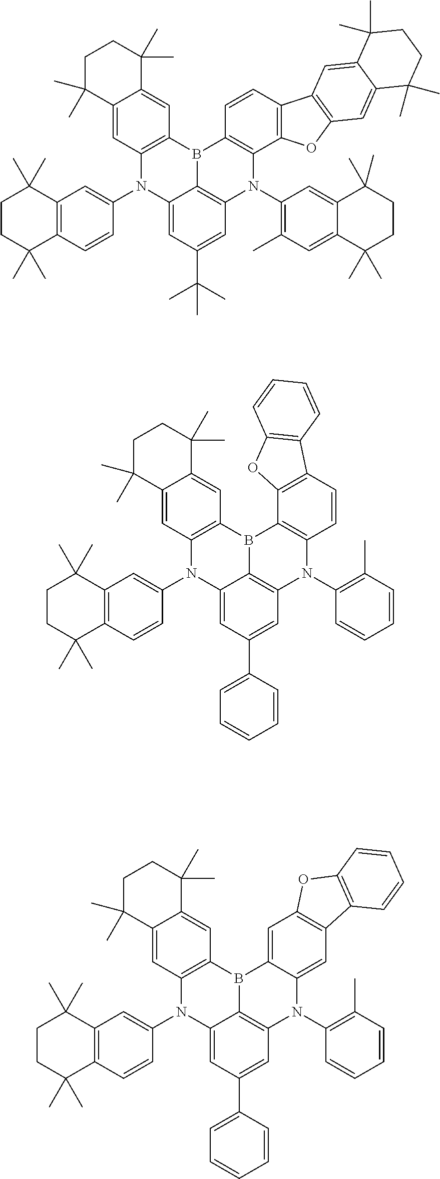 [SMILES: Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c31)C(C)(C)CCC2(C)C ; Cc1ccccc1N1c2cc(-c3ccccc3)cc3c2B(c2cc4c(cc2N3c2ccc3c(c2)C(C)(C)CCC3(C)C)C(C)(C)CCC4(C)C)c2c1ccc1c2oc2ccccc21 ; Cc1ccccc1N1c2cc3c(cc2B2c4cc5c(cc4N(c4ccc6c(c4)C(C)(C)CCC6(C)C)c4cc(-c6ccccc6)cc1c42)C(C)(C)CCC5(C)C)oc1ccccc13]

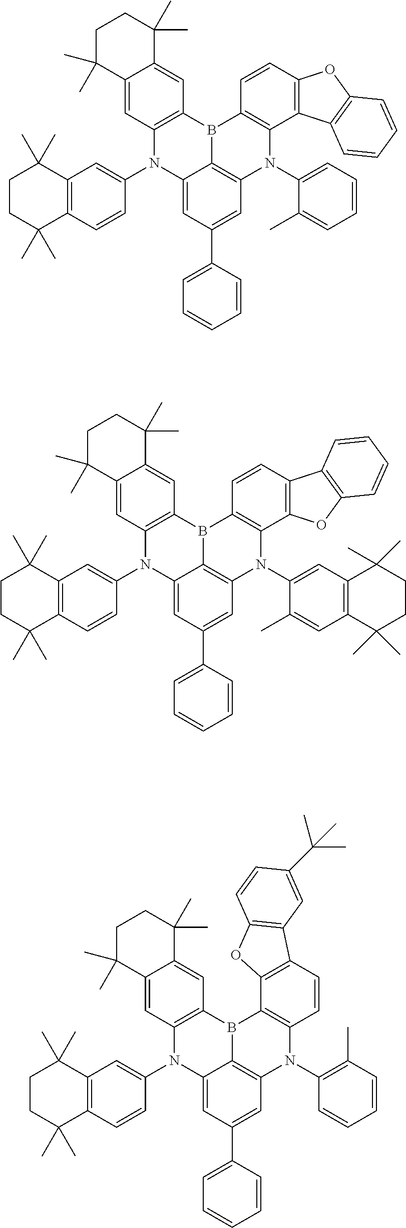 [SMILES: Cc1ccccc1N1c2cc(-c3ccccc3)cc3c2B(c2cc4c(cc2N3c2ccc3c(c2)C(C)(C)CCC3(C)C)C(C)(C)CCC4(C)C)c2ccc3oc4ccccc4c3c21 ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3ccc4c(oc5ccccc54)c31)C(C)(C)CCC2(C)C ; Cc1ccccc1N1c2cc(-c3ccccc3)cc3c2B(c2cc4c(cc2N3c2ccc3c(c2)C(C)(C)CCC3(C)C)C(C)(C)CCC4(C)C)c2c1ccc1c2oc2ccc(C(C)(C)C)cc21]

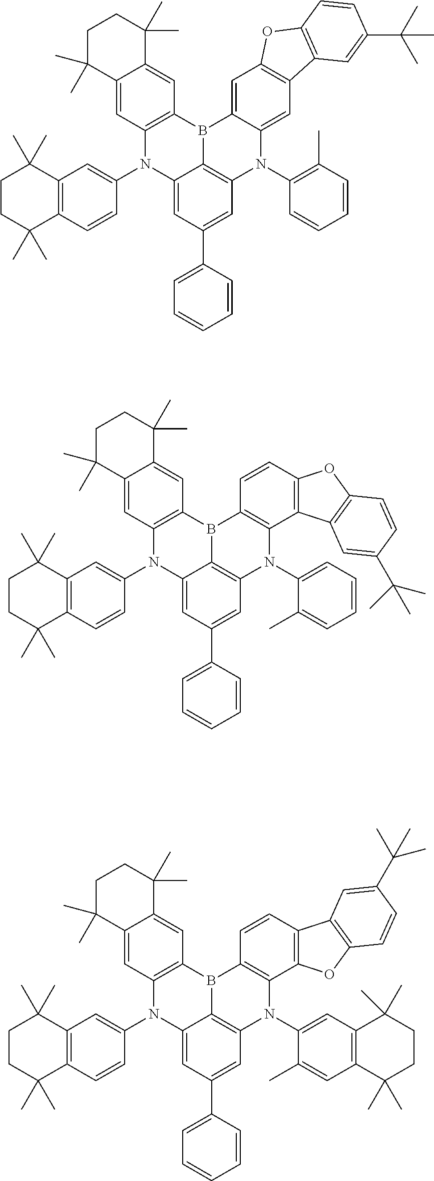 [SMILES: Cc1ccccc1N1c2cc3c(cc2B2c4cc5c(cc4N(c4ccc6c(c4)C(C)(C)CCC6(C)C)c4cc(-c6ccccc6)cc1c42)C(C)(C)CCC5(C)C)oc1ccc(C(C)(C)C)cc13 ; Cc1ccccc1N1c2cc(-c3ccccc3)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21 ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C]

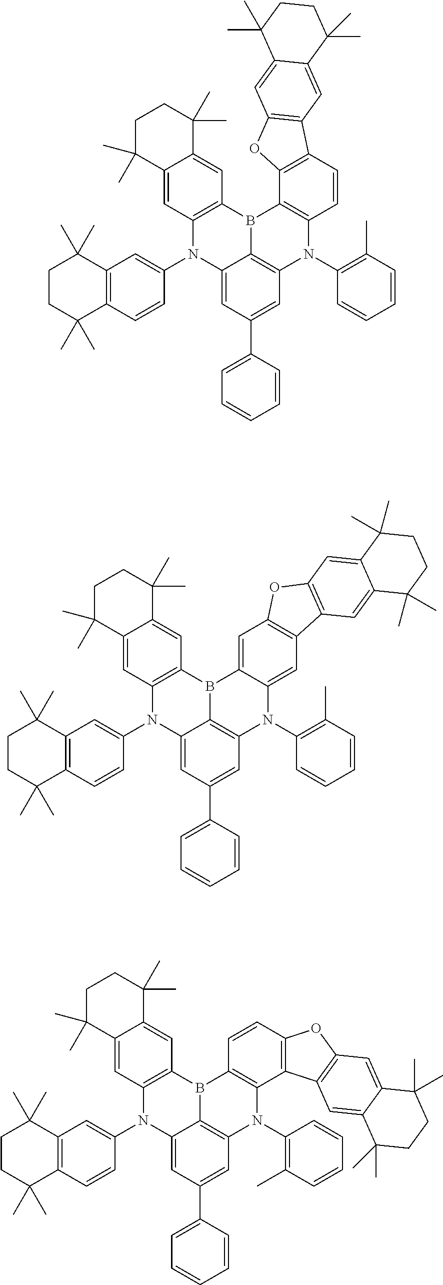 [SMILES: Cc1ccccc1N1c2cc(-c3ccccc3)cc3c2B(c2cc4c(cc2N3c2ccc3c(c2)C(C)(C)CCC3(C)C)C(C)(C)CCC4(C)C)c2c1ccc1c2oc2cc3c(cc21)C(C)(C)CCC3(C)C ; Cc1ccccc1N1c2cc3c(cc2B2c4cc5c(cc4N(c4ccc6c(c4)C(C)(C)CCC6(C)C)c4cc(-c6ccccc6)cc1c42)C(C)(C)CCC5(C)C)oc1cc2c(cc13)C(C)(C)CCC2(C)C ; Cc1ccccc1N1c2cc(-c3ccccc3)cc3c2B(c2cc4c(cc2N3c2ccc3c(c2)C(C)(C)CCC3(C)C)C(C)(C)CCC4(C)C)c2ccc3oc4cc5c(cc4c3c21)C(C)(C)CCC5(C)C]

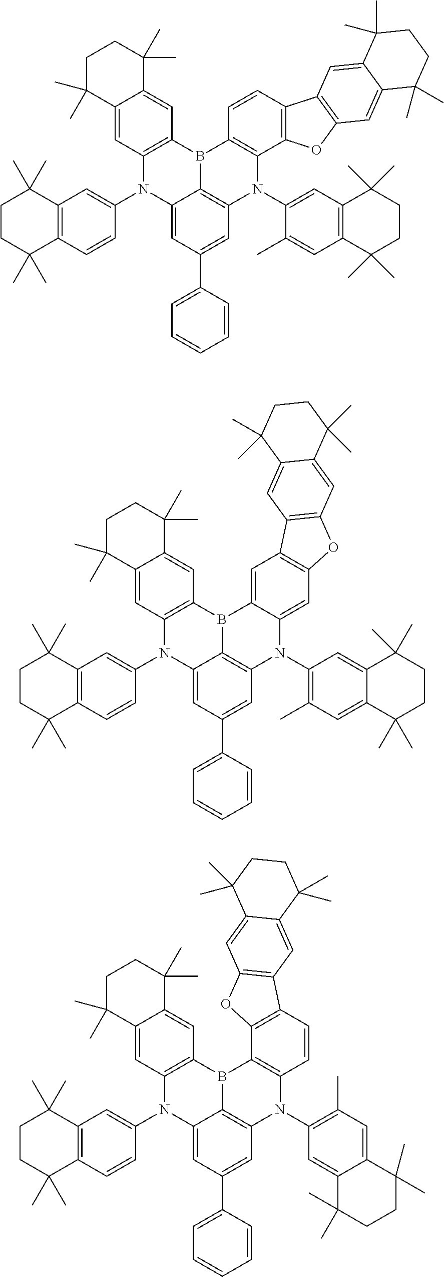

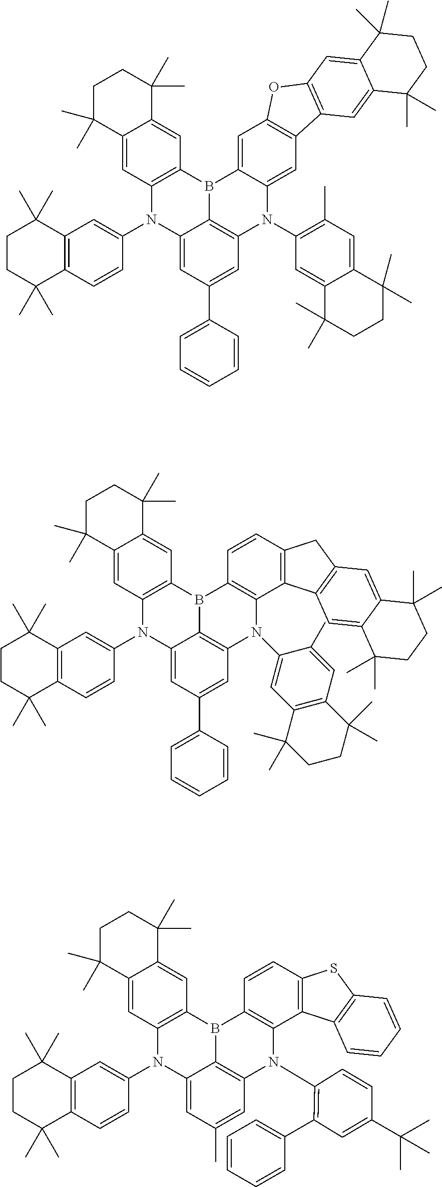

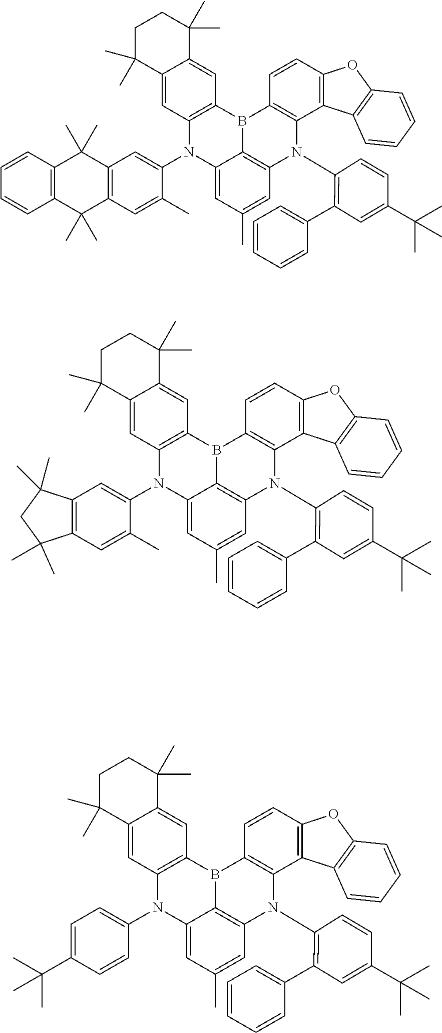

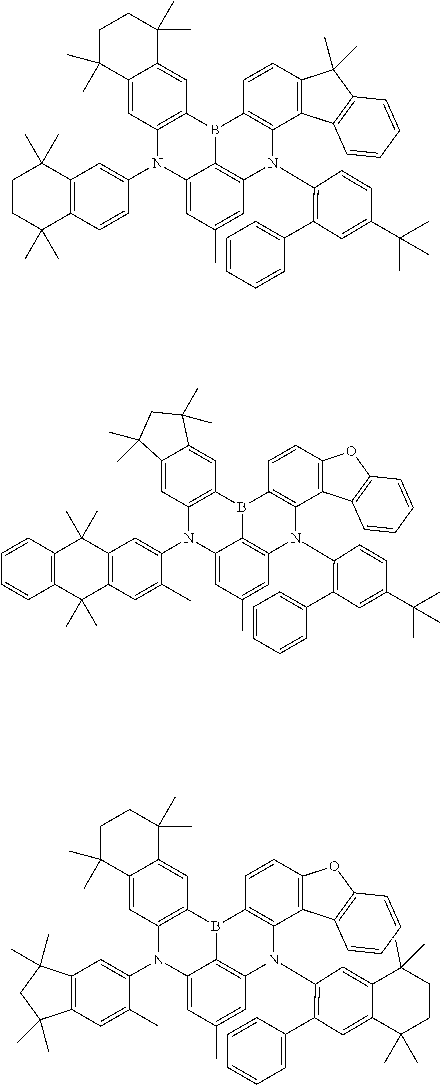

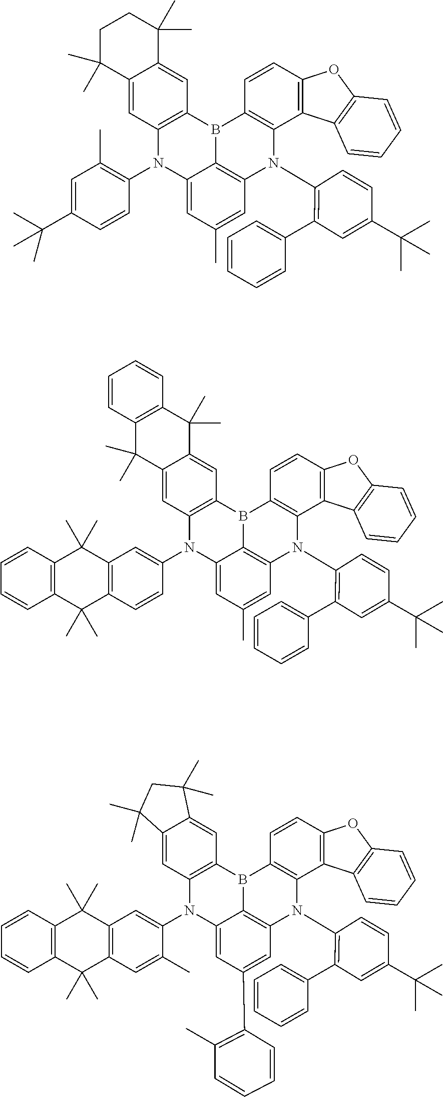 [SMILES: Cc1cc2c3c(c1)N(c1ccc(C(C)(C)C)cc1-c1ccccc1)c1c(ccc4oc5ccccc5c14)B3c1cc3c(cc1N2c1ccc(C(C)(C)C)cc1C)C(C)(C)CCC3(C)C ; Cc1cc2c3c(c1)N(c1ccc(C(C)(C)C)cc1-c1ccccc1)c1c(ccc4oc5ccccc5c14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)c1ccccc1C2(C)C)C(C)(C)CC3(C)C]

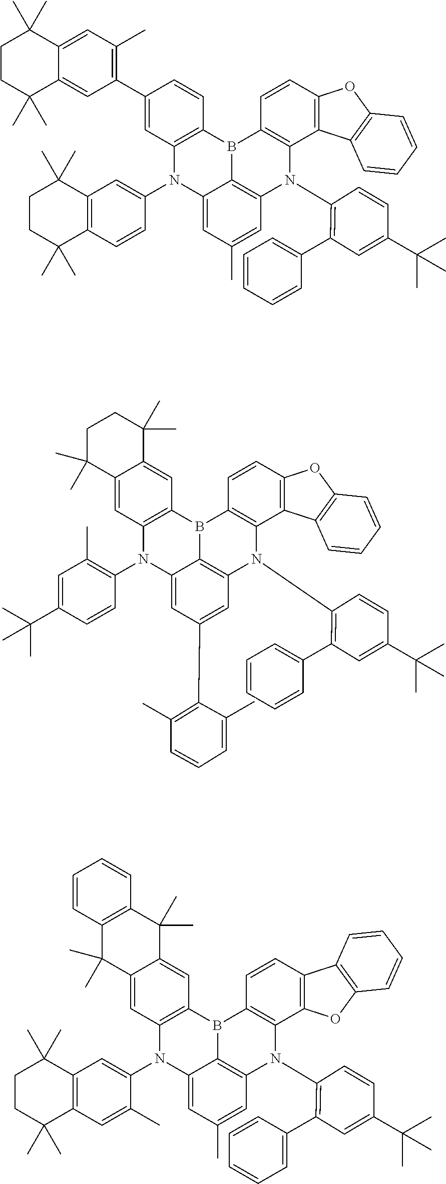

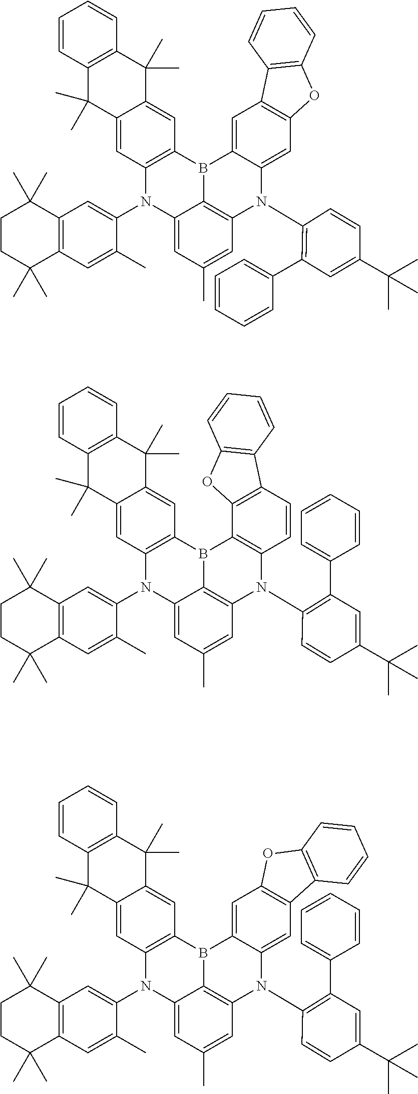 [SMILES: Cc1cc2c3c(c1)N(c1ccc(C(C)(C)C)cc1-c1ccccc1)c1cc4oc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1ccc4c(oc5ccccc54)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1ccccc14]

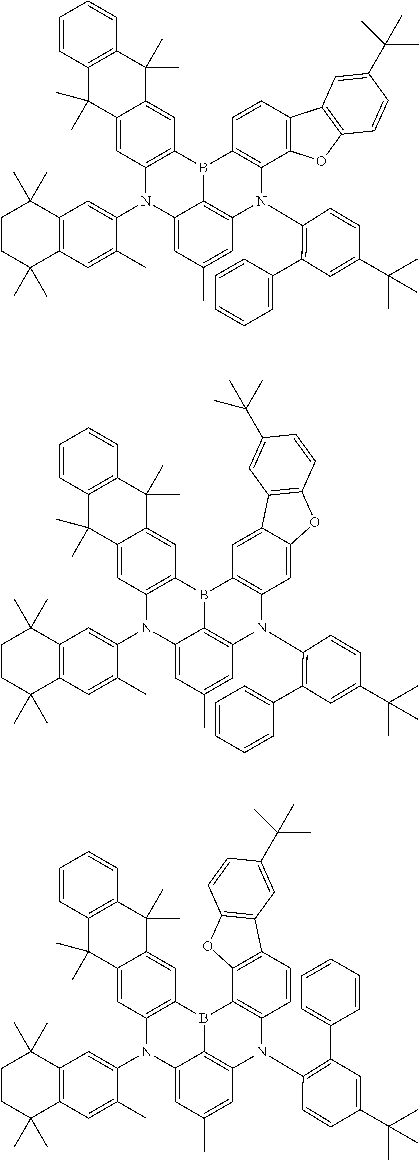 [SMILES: Cc1cc2c3c(c1)N(c1ccc(C(C)(C)C)cc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C]

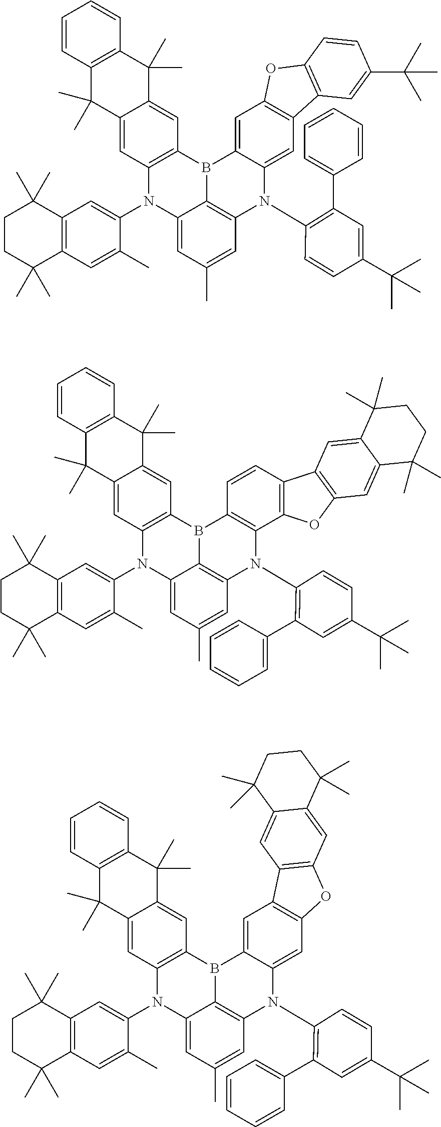 [SMILES: Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

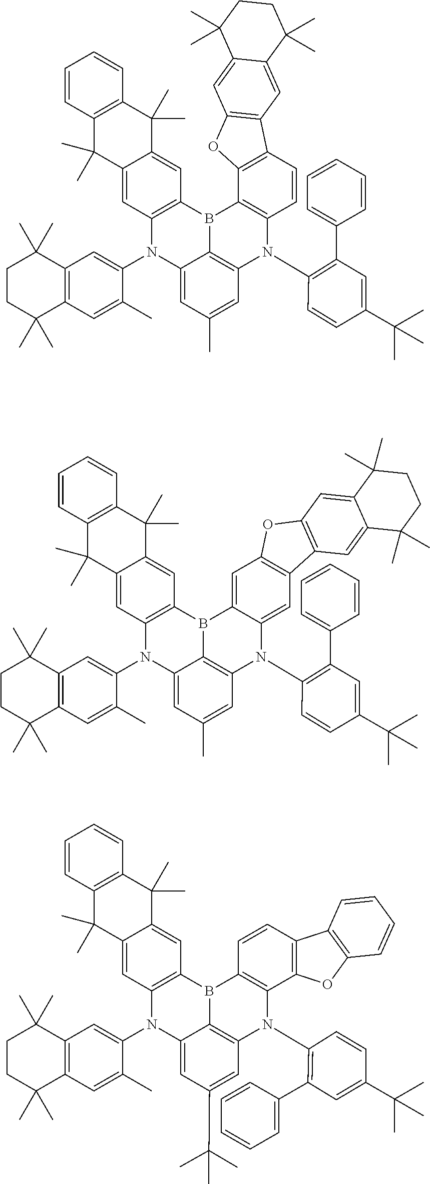 [SMILES: Cc1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C ; Cc1cc2c(cc1N1c3cc4c(cc3B3c5ccc6c(oc7ccccc76)c5N(c5ccc(C(C)(C)C)cc5-c5ccccc5)c5cc(C(C)(C)C)cc1c53)C(C)(C)c1ccccc1C4(C)C)C(C)(C)CCC2(C)C]

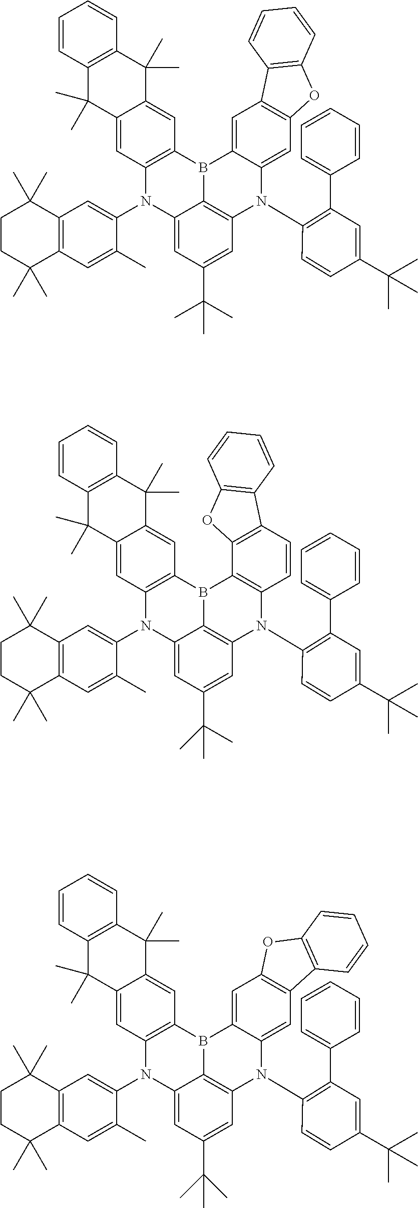 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)oc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C]

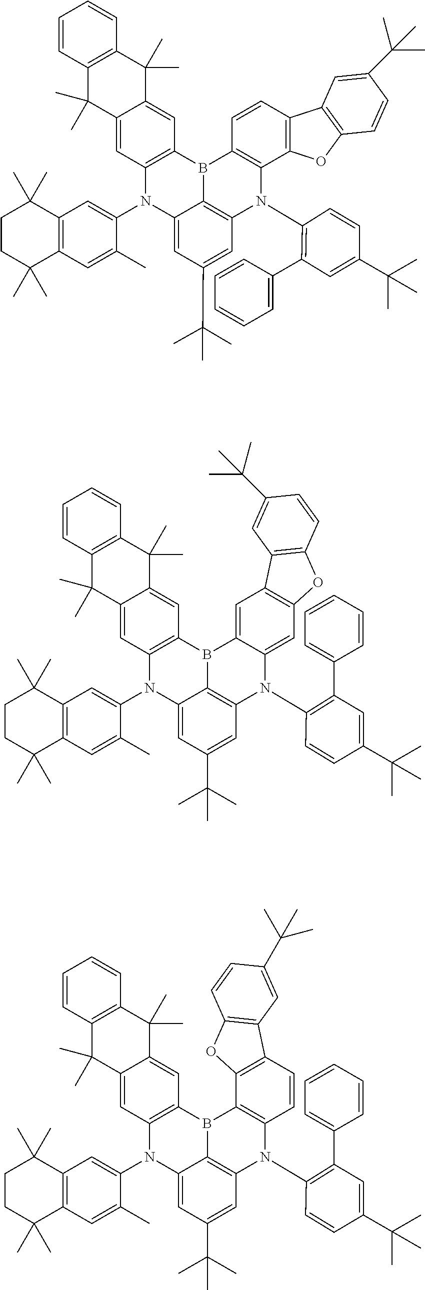 [SMILES: Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(oc6ccc(C(C)(C)C)cc65)c13)C(C)(C)c1ccccc1C4(C)C)C(C)(C)CCC2(C)C]

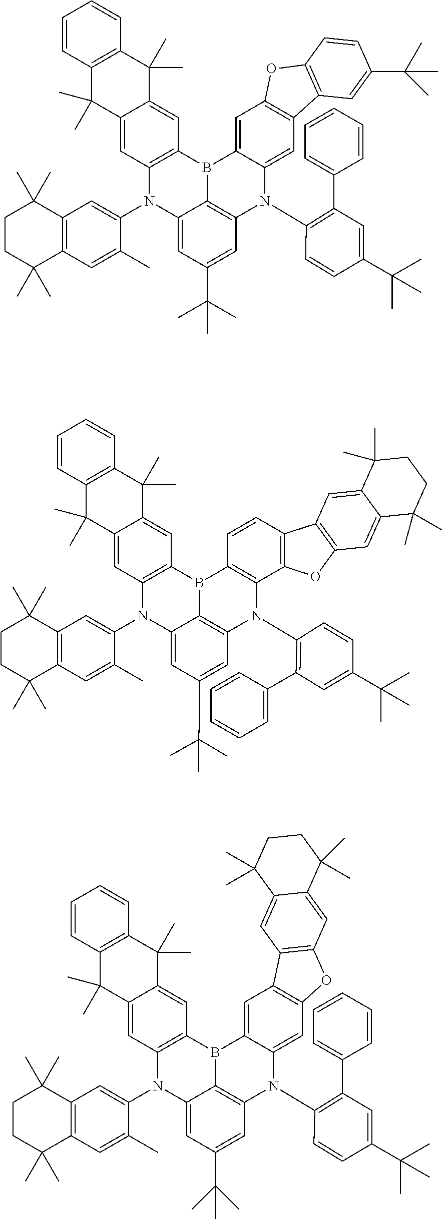 [SMILES: Cc1cc2c(cc1N1c3cc4c(cc3B3c5cc6oc7ccc(C(C)(C)C)cc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)oc1cc3c(cc16)C(C)(C)CCC3(C)C)C(C)(C)c1ccccc1C4(C)C)C(C)(C)CCC2(C)C]

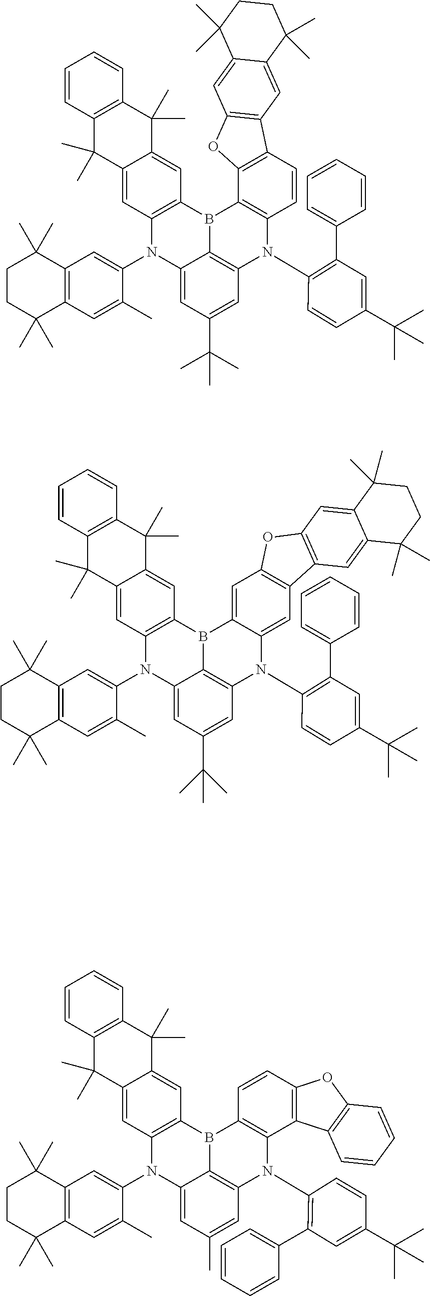 [SMILES: Cc1cc2c(cc1N1c3cc4c(cc3B3c5c1cc(C(C)(C)C)cc5N(c1ccc(C(C)(C)C)cc1-c1ccccc1)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)CCC2(C)C)C(C)(C)c1ccccc1C3(C)C]

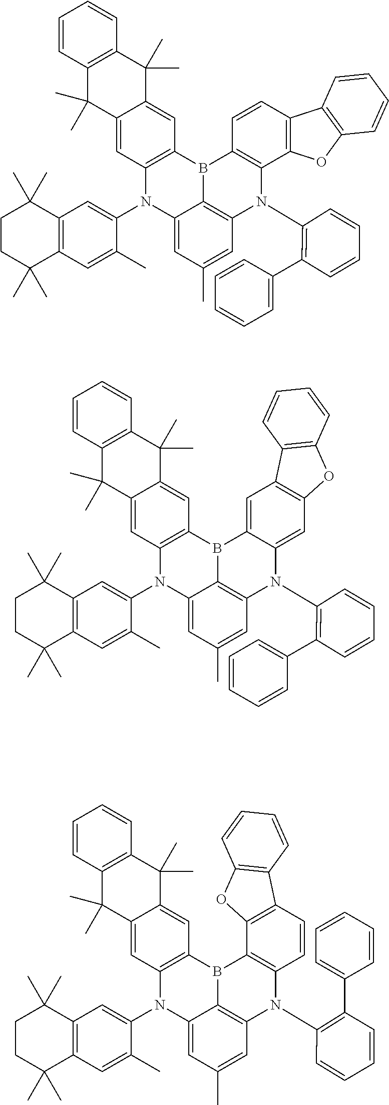 [SMILES: Cc1cc2c3c(c1)N(c1ccccc1-c1ccccc1)c1c(ccc4c1oc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4oc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1ccc4c(oc5ccccc54)c1B3c1cc3c(cc1N2c1cc2c(cc1C)C(C)(C)CCC2(C)C)C(C)(C)c1ccccc1C3(C)C]

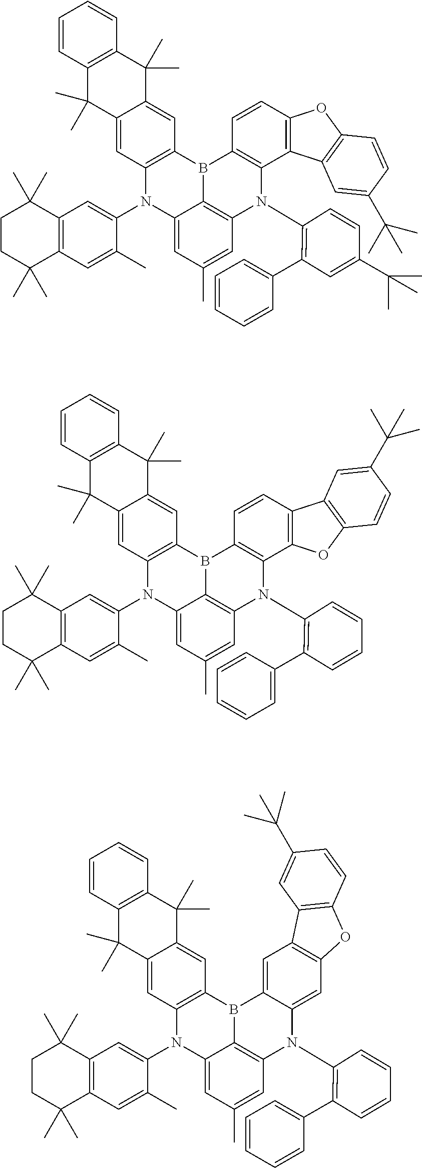 [SMILES: Cc1cc2c3c(c1)N(c1ccc(C(C)(C)C)cc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C]

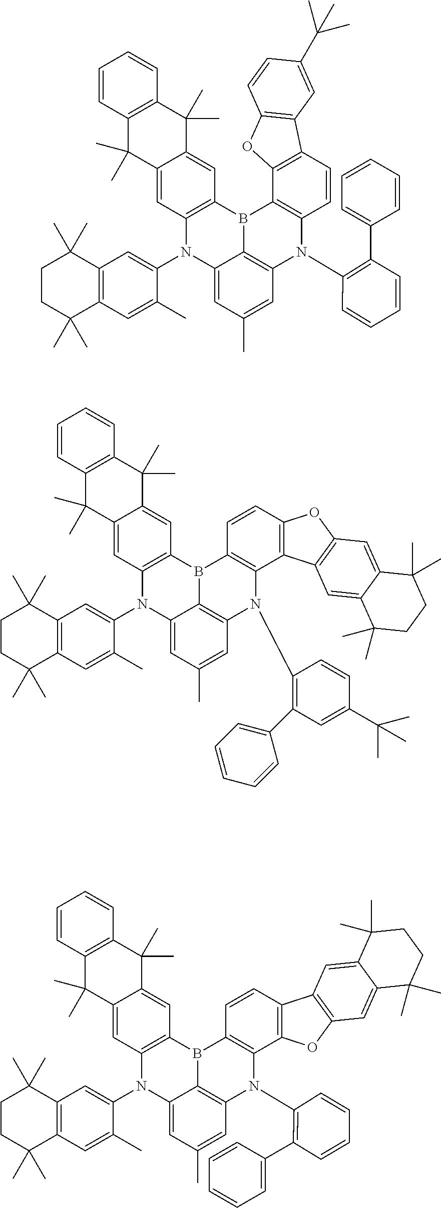 [SMILES: Cc1cc2c3c(c1)N(c1ccccc1-c1ccccc1)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

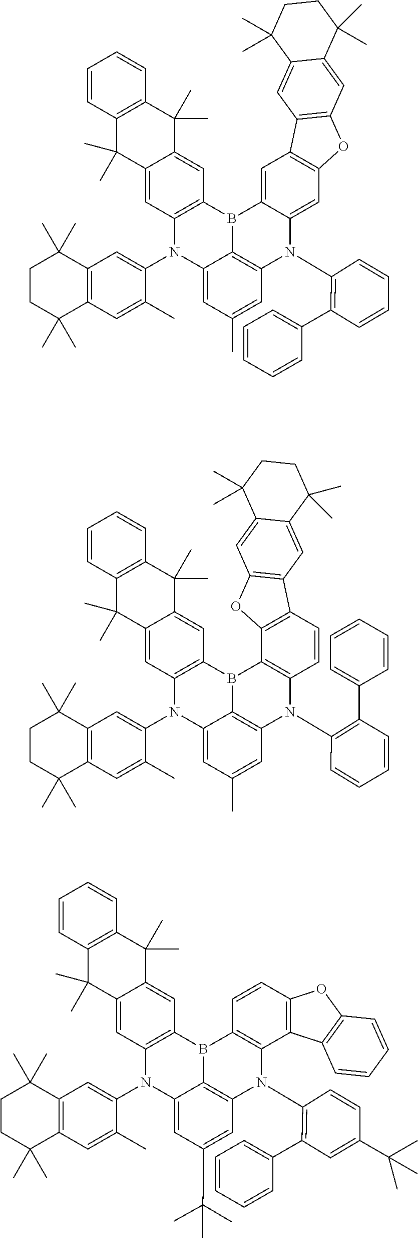 [SMILES: Cc1cc2c3c(c1)N(c1ccccc1-c1ccccc1)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1cc2c3c(c1)N(c1ccccc1-c1ccccc1)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1cc2c(cc1N1c3cc4c(cc3B3c5ccc6oc7ccccc7c6c5N(c5ccc(C(C)(C)C)cc5-c5ccccc5)c5cc(C(C)(C)C)cc1c53)C(C)(C)c1ccccc1C4(C)C)C(C)(C)CCC2(C)C]

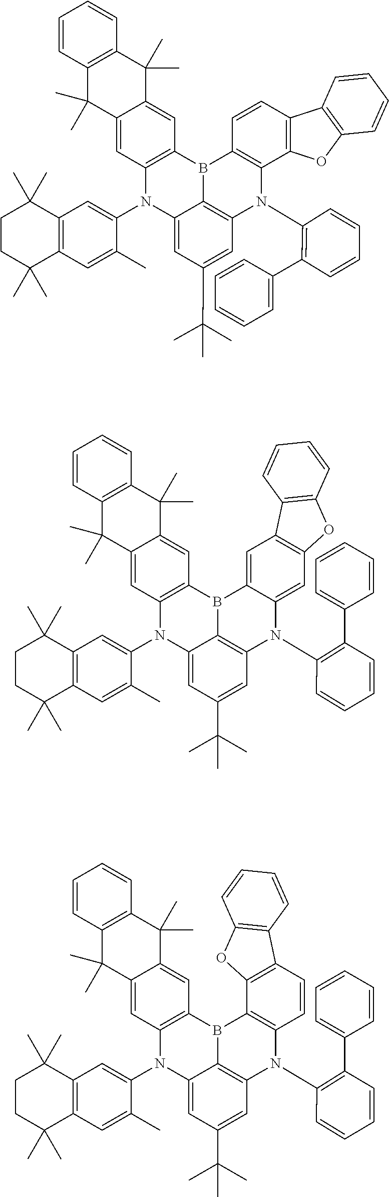 [SMILES: Cc1cc2c(cc1N1c3cc4c(cc3B3c5ccc6c(oc7ccccc76)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)oc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(oc6ccccc65)c13)C(C)(C)c1ccccc1C4(C)C)C(C)(C)CCC2(C)C]

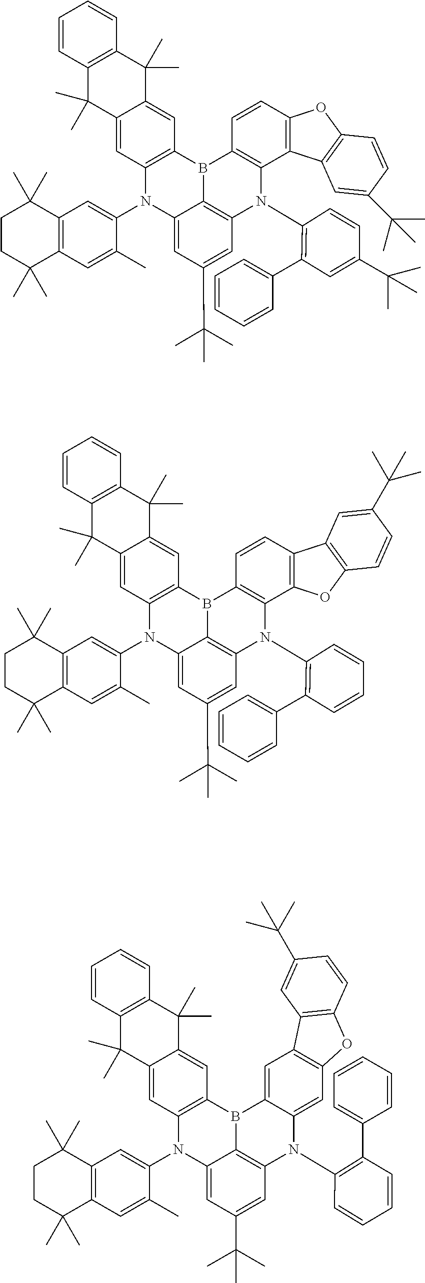 [SMILES: Cc1cc2c(cc1N1c3cc4c(cc3B3c5ccc6oc7ccc(C(C)(C)C)cc7c6c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)oc1ccc(C(C)(C)C)cc16)C(C)(C)c1ccccc1C4(C)C)C(C)(C)CCC2(C)C]

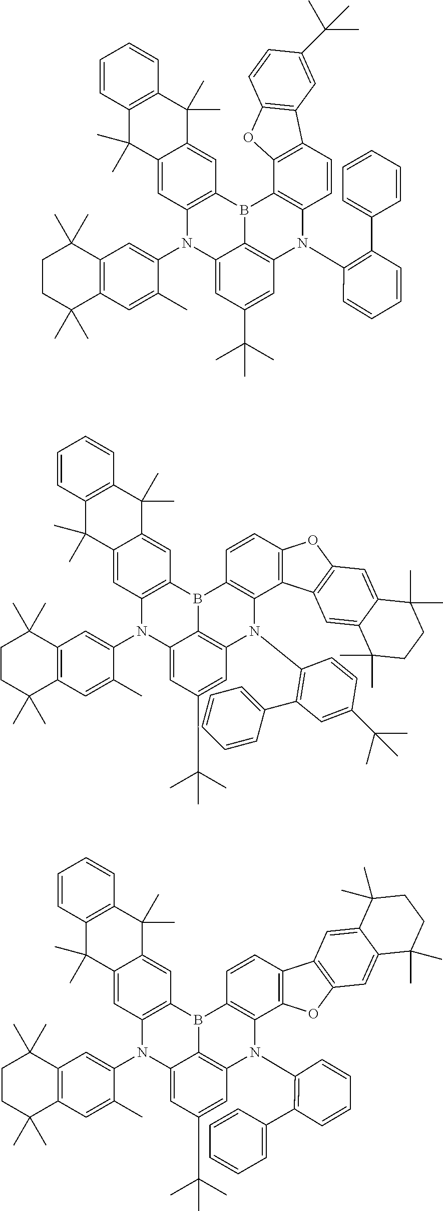 [SMILES: Cc1cc2c(cc1N1c3cc4c(cc3B3c5c1cc(C(C)(C)C)cc5N(c1ccccc1-c1ccccc1)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5-c5ccccc5)c5cc(C(C)(C)C)cc1c53)C(C)(C)c1ccccc1C4(C)C)C(C)(C)CCC2(C)C]

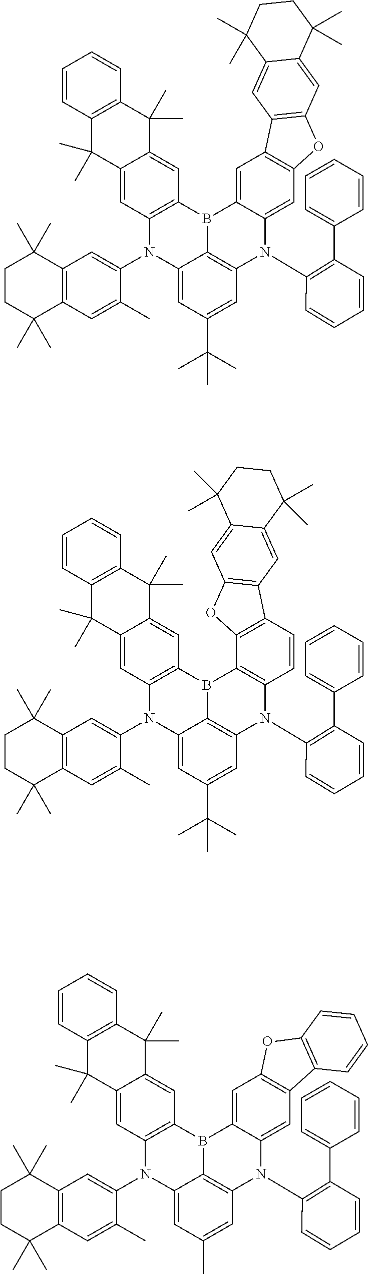 [SMILES: Cc1cc2c(cc1N1c3cc4c(cc3B3c5cc6c(cc5N(c5ccccc5-c5ccccc5)c5cc(C(C)(C)C)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(oc6cc7c(cc65)C(C)(C)CCC7(C)C)c13)C(C)(C)c1ccccc1C4(C)C)C(C)(C)CCC2(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1ccccc14]

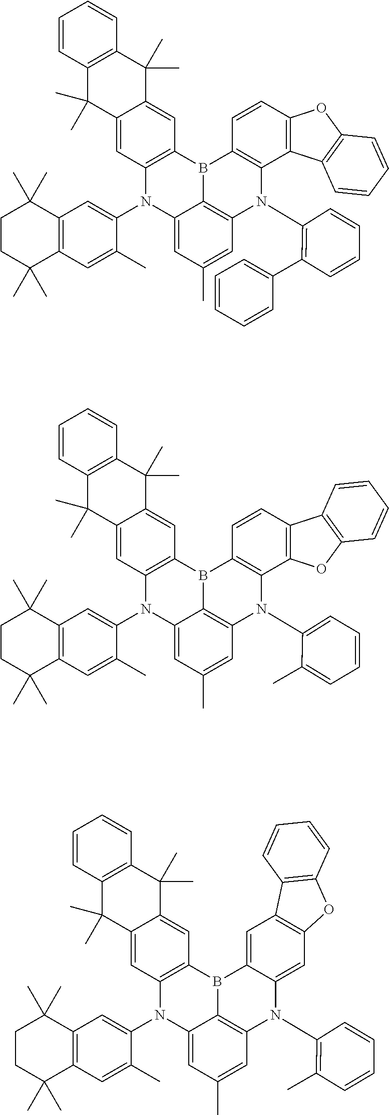 [SMILES: Cc1cc2c3c(c1)N(c1ccccc1-c1ccccc1)c1c(ccc4oc5ccccc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1c(ccc4c1oc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4oc5ccccc5c4cc1B3c1cc3c(cc1N2c1cc2c(cc1C)C(C)(C)CCC2(C)C)C(C)(C)c1ccccc1C3(C)C]

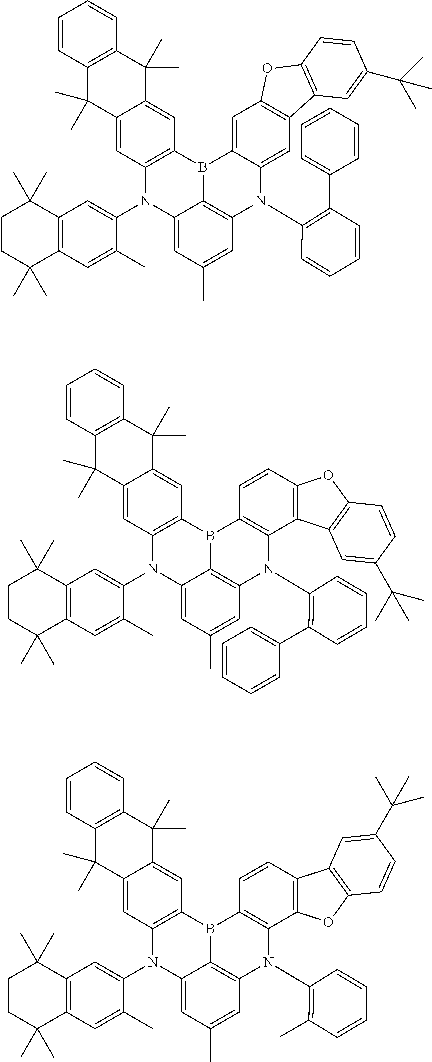 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1cc2c3c(c1)N(c1ccccc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C]

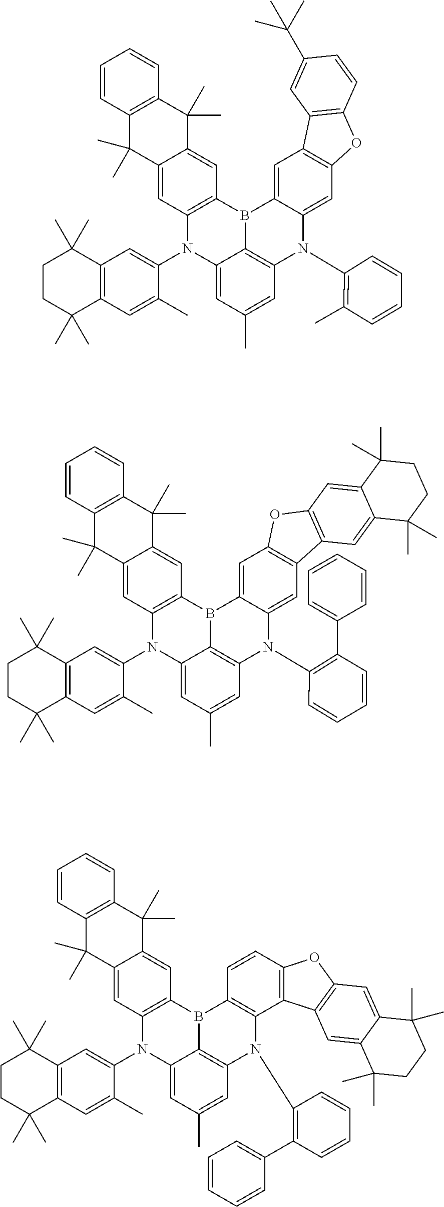 [SMILES: Cc1cc2c3c(c1)N(c1ccccc1C)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C ; Cc1cc2c3c(c1)N(c1ccccc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C]

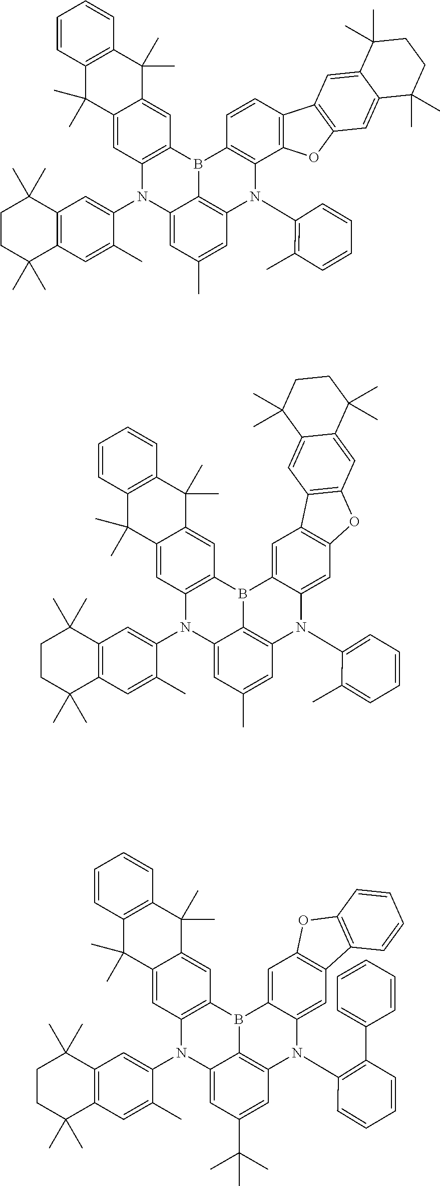 [SMILES: Cc1cc2c3c(c1)N(c1ccccc1C)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1cc2c(cc1N1c3cc4c(cc3B3c5cc6oc7ccccc7c6cc5N(c5ccccc5-c5ccccc5)c5cc(C(C)(C)C)cc1c53)C(C)(C)c1ccccc1C4(C)C)C(C)(C)CCC2(C)C]

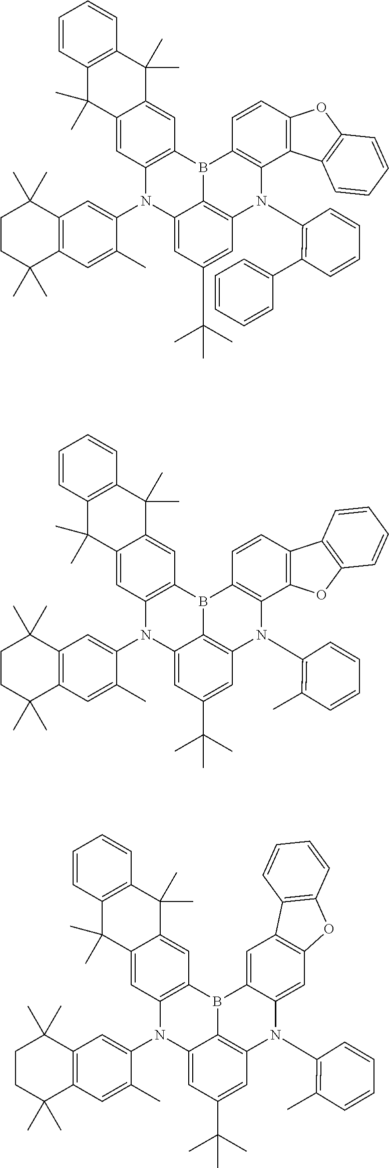 [SMILES: Cc1cc2c(cc1N1c3cc4c(cc3B3c5ccc6oc7ccccc7c6c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5C)c5cc(C(C)(C)C)cc1c53)C(C)(C)c1ccccc1C4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(C(C)(C)C)cc1c32)C(C)(C)c1ccccc1C4(C)C]

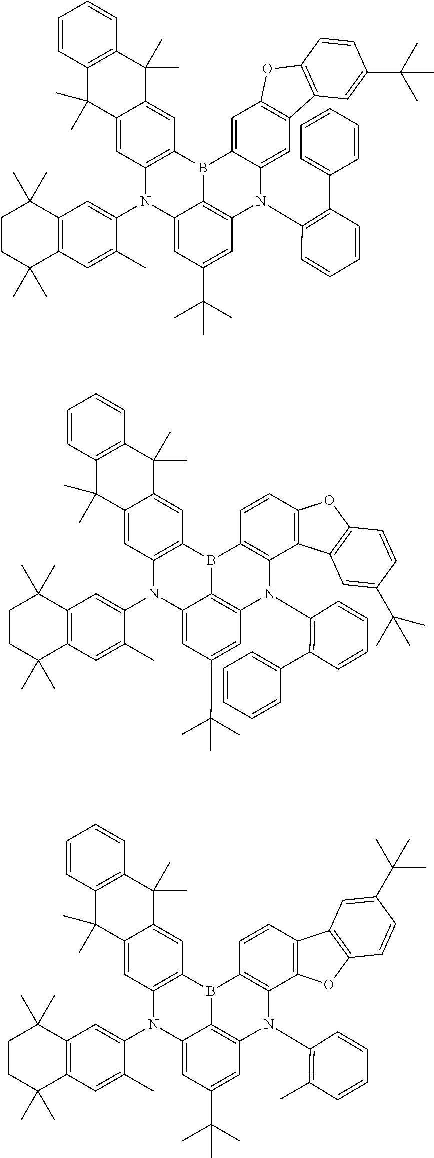 [SMILES: Cc1cc2c(cc1N1c3cc4c(cc3B3c5cc6oc7ccc(C(C)(C)C)cc7c6cc5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6oc7ccc(C(C)(C)C)cc7c6c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5C)c5cc(C(C)(C)C)cc1c53)C(C)(C)c1ccccc1C4(C)C)C(C)(C)CCC2(C)C]

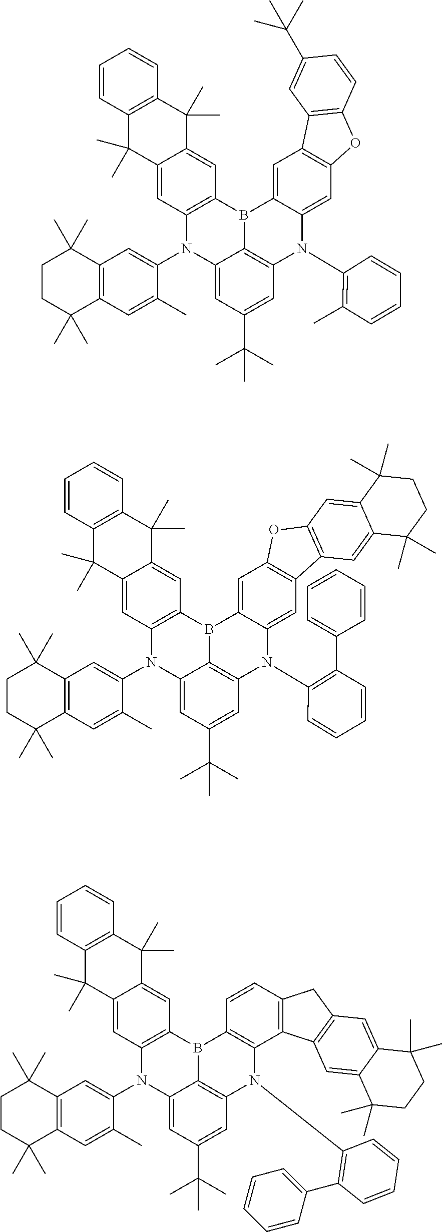 [SMILES: Cc1ccccc1N1c2cc3oc4ccc(C(C)(C)C)cc4c3cc2B2c3cc4c(cc3N(c3cc5c(cc3C)C(C)(C)CCC5(C)C)c3cc(C(C)(C)C)cc1c32)C(C)(C)c1ccccc1C4(C)C ; Cc1cc2c(cc1N1c3cc4c(cc3B3c5cc6oc7cc8c(cc7c6cc5N(c5ccccc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)-c1cc3c(cc1C6)C(C)(C)CCC3(C)C)C(C)(C)c1ccccc1C4(C)C)C(C)(C)CCC2(C)C]

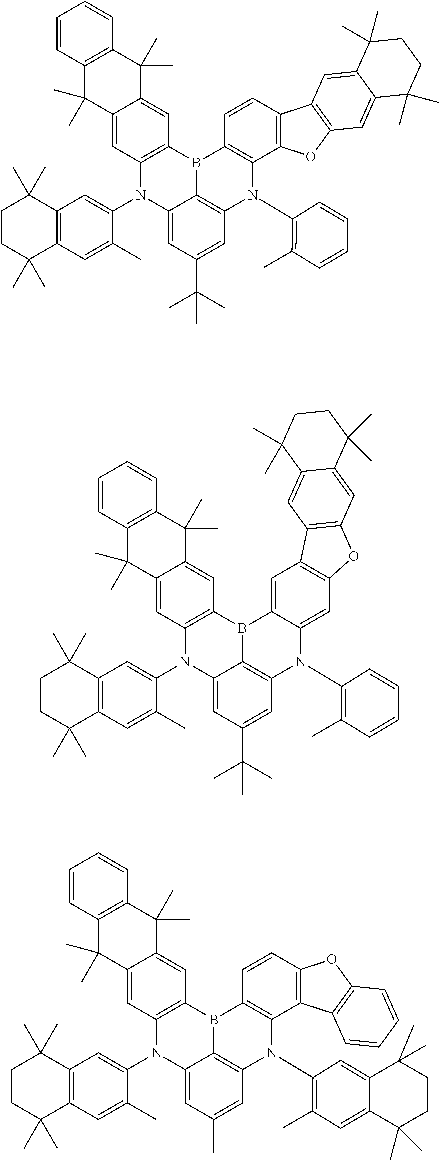 [SMILES: Cc1cc2c(cc1N1c3cc4c(cc3B3c5ccc6c(oc7cc8c(cc76)C(C)(C)CCC8(C)C)c5N(c5ccccc5C)c5cc(C(C)(C)C)cc1c53)C(C)(C)c1ccccc1C4(C)C)C(C)(C)CCC2(C)C ; Cc1ccccc1N1c2cc3oc4cc5c(cc4c3cc2B2c3cc4c(cc3N(c3cc6c(cc3C)C(C)(C)CCC6(C)C)c3cc(C(C)(C)C)cc1c32)C(C)(C)c1ccccc1C4(C)C)C(C)(C)CCC5(C)C ; Cc1cc2c3c(c1)N(c1cc4c(cc1C)C(C)(C)CCC4(C)C)c1c(ccc4oc5ccccc5c14)B3c1cc3c(cc1N2c1cc2c(cc1C)C(C)(C)CCC2(C)C)C(C)(C)c1ccccc1C3(C)C]

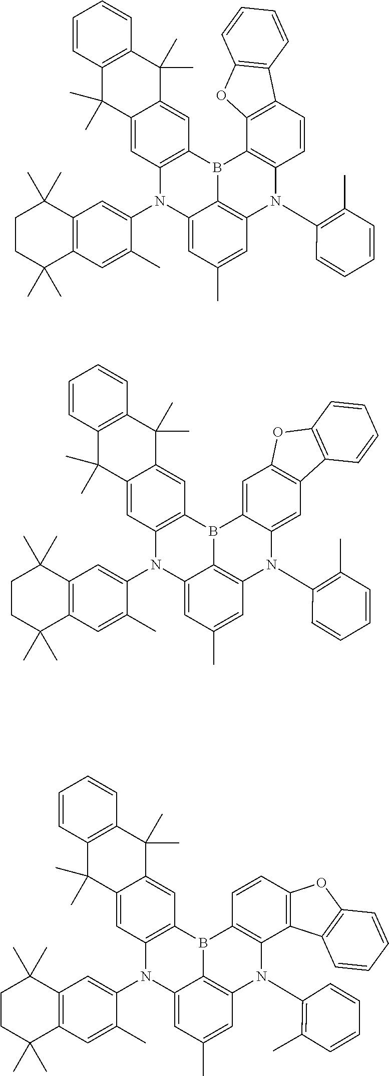 [SMILES: Cc1cc2c3c(c1)N(c1ccccc1C)c1ccc4c(oc5ccccc54)c1B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1ccccc14 ; Cc1cc2c3c(c1)N(c1ccccc1C)c1c(ccc4oc5ccccc5c14)B3c1cc3c(cc1N2c1cc2c(cc1C)C(C)(C)CCC2(C)C)C(C)(C)c1ccccc1C3(C)C]

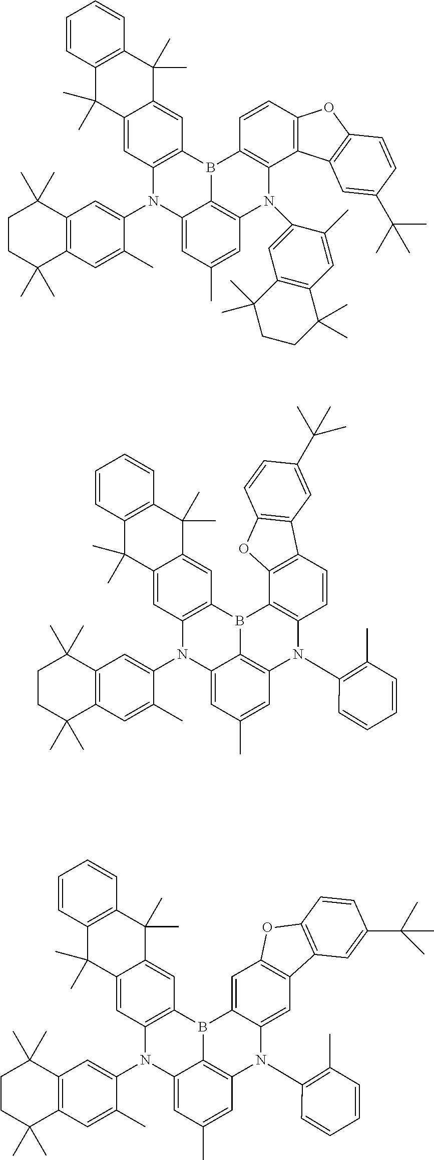 [SMILES: Cc1cc2c3c(c1)N(c1cc4c(cc1C)C(C)(C)CCC4(C)C)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14]

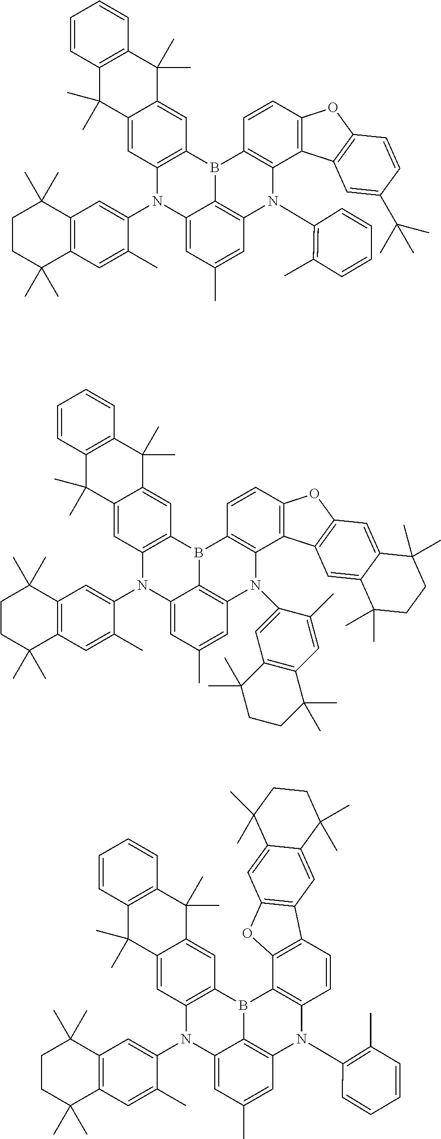 [SMILES: Cc1cc2c3c(c1)N(c1ccccc1C)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C]

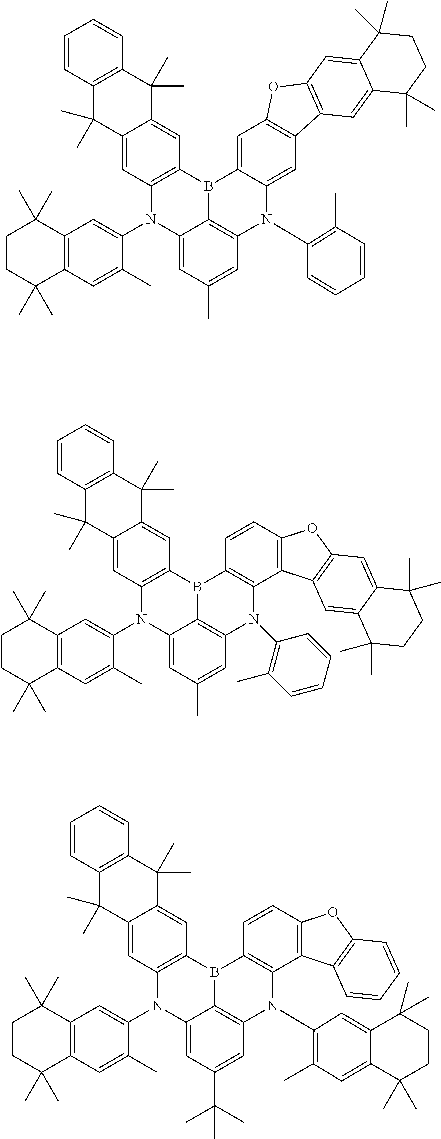 [SMILES: Cc1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C ; Cc1cc2c3c(c1)N(c1ccccc1C)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1cc2c(cc1N1c3cc4c(cc3B3c5ccc6oc7ccccc7c6c5N(c5cc6c(cc5C)C(C)(C)CCC6(C)C)c5cc(C(C)(C)C)cc1c53)C(C)(C)c1ccccc1C4(C)C)C(C)(C)CCC2(C)C]

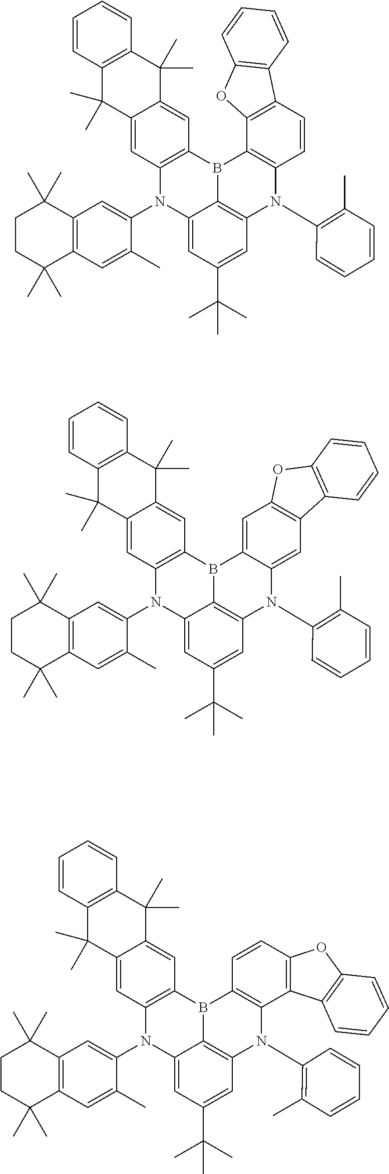 [SMILES: Cc1cc2c(cc1N1c3cc4c(cc3B3c5c1cc(C(C)(C)C)cc5N(c1ccccc1C)c1ccc5c(oc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)oc1ccccc13 ; Cc1cc2c(cc1N1c3cc4c(cc3B3c5ccc6oc7ccccc7c6c5N(c5ccccc5C)c5cc(C(C)(C)C)cc1c53)C(C)(C)c1ccccc1C4(C)C)C(C)(C)CCC2(C)C]

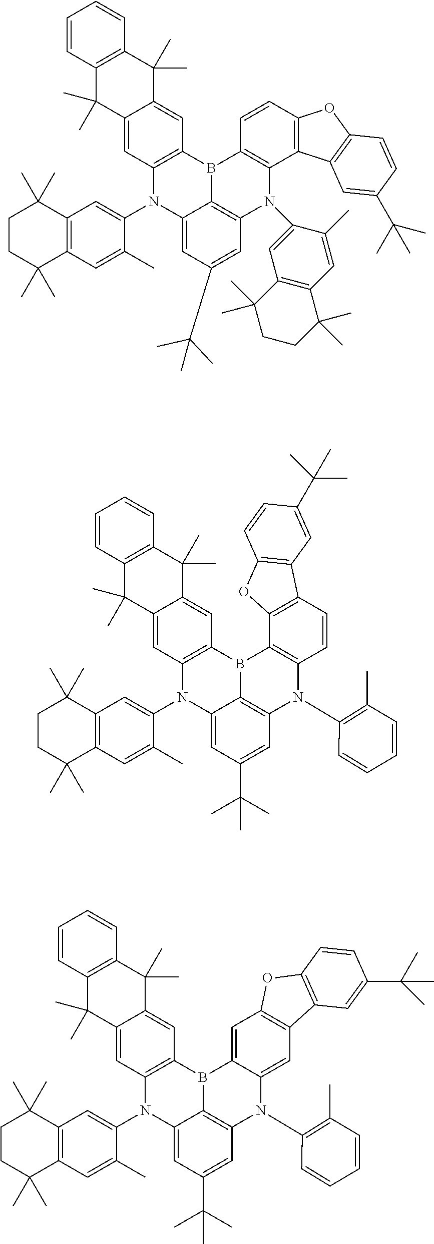 [SMILES: Cc1cc2c(cc1N1c3cc4c(cc3B3c5ccc6oc7ccc(C(C)(C)C)cc7c6c5N(c5cc6c(cc5C)C(C)(C)CCC6(C)C)c5cc(C(C)(C)C)cc1c53)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1C)c1ccc5c(oc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)oc1ccc(C(C)(C)C)cc13]

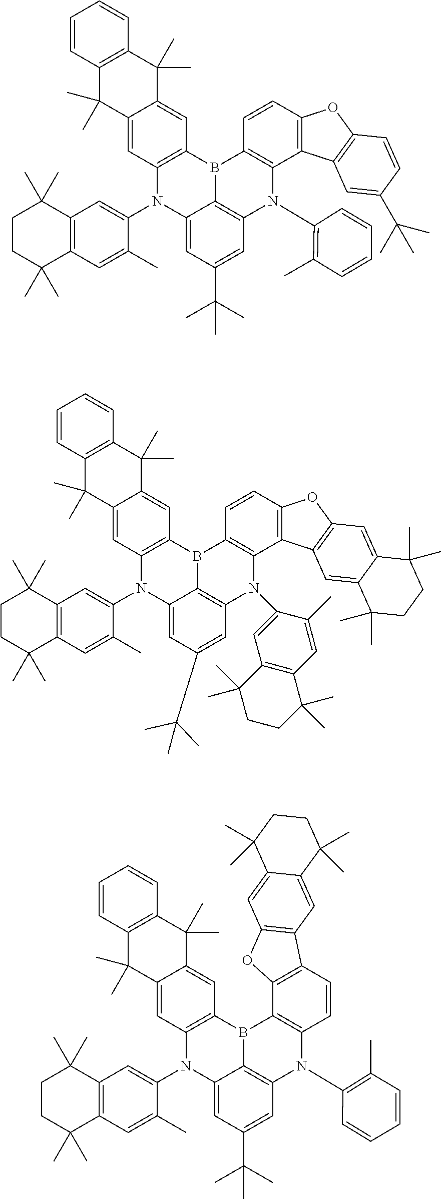 [SMILES: Cc1cc2c(cc1N1c3cc4c(cc3B3c5ccc6oc7ccc(C(C)(C)C)cc7c6c5N(c5ccccc5C)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5cc6c(cc5C)C(C)(C)CCC6(C)C)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1C)c1ccc5c(oc6cc7c(cc65)C(C)(C)CCC7(C)C)c13)C(C)(C)c1ccccc1C4(C)C)C(C)(C)CCC2(C)C]

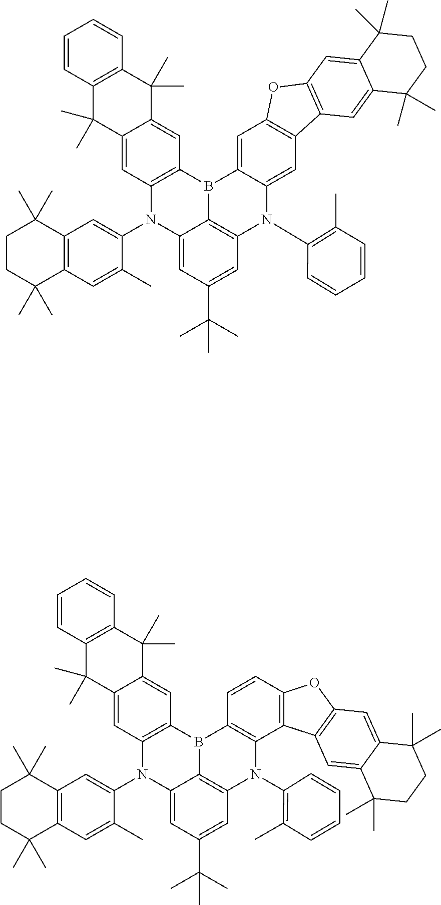 [SMILES: Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)oc1cc2c(cc13)C(C)(C)CCC2(C)C ; Cc1cc2c(cc1N1c3cc4c(cc3B3c5ccc6oc7cc8c(cc7c6c5N(c5ccccc5C)c5cc(C(C)(C)C)cc1c53)C(C)(C)CCC8(C)C)C(C)(C)c1ccccc1C4(C)C)C(C)(C)CCC2(C)C]

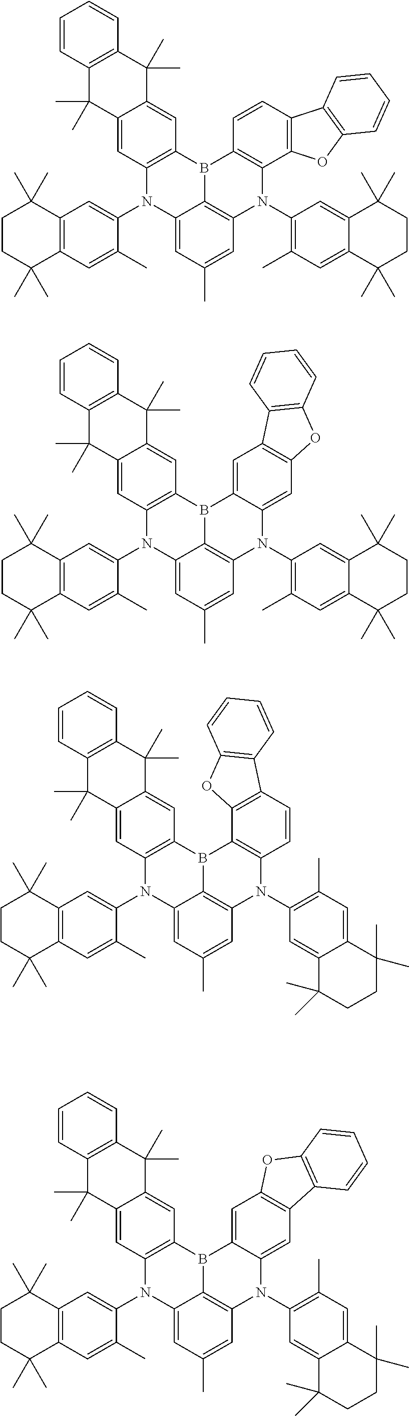

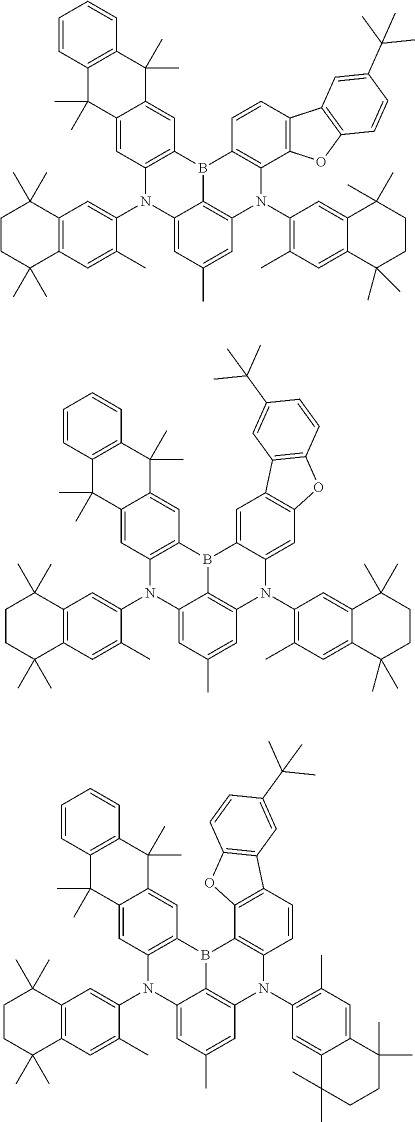 [SMILES: Cc1cc2c3c(c1)N(c1cc4c(cc1C)C(C)(C)CCC4(C)C)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C]

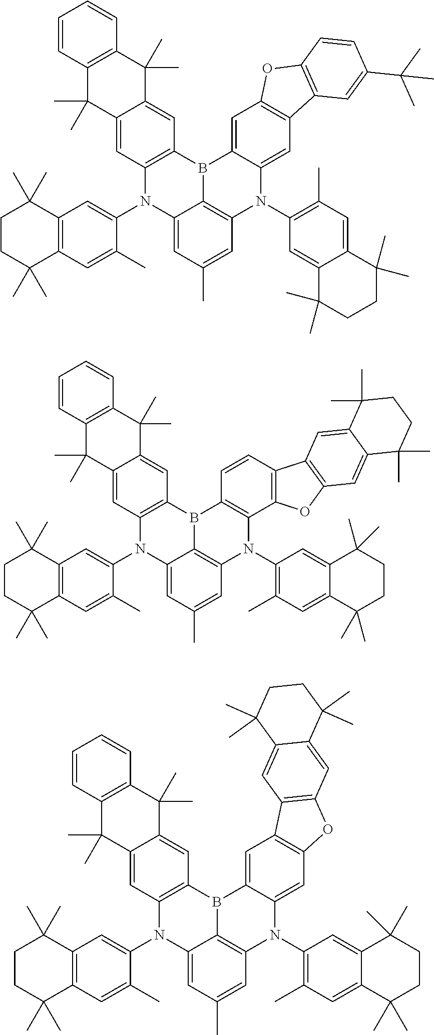 [SMILES: Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

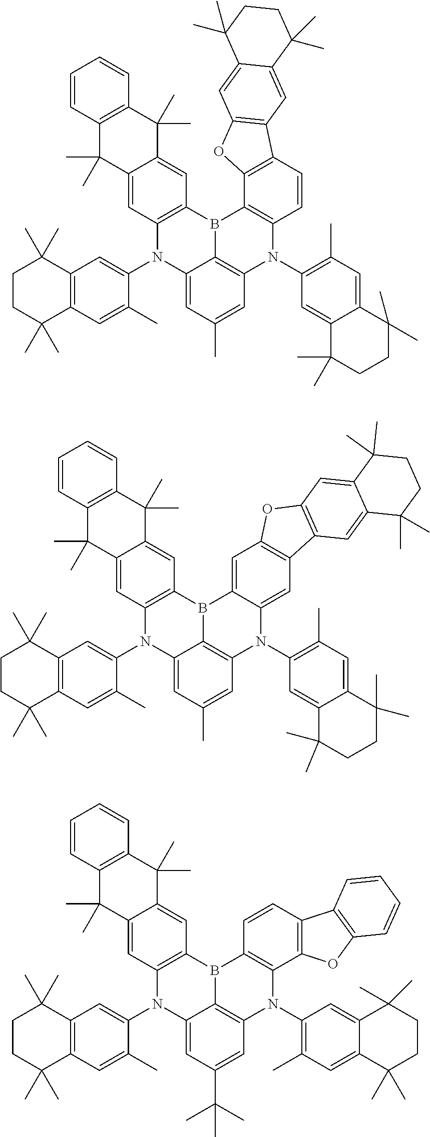 [SMILES: Cc1cc2c3c(c1)N(c1cc4c(cc1C)C(C)(C)CCC4(C)C)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(C(C)(C)C)cc1c53)C(C)(C)c1ccccc1C4(C)C)C(C)(C)CCC2(C)C]

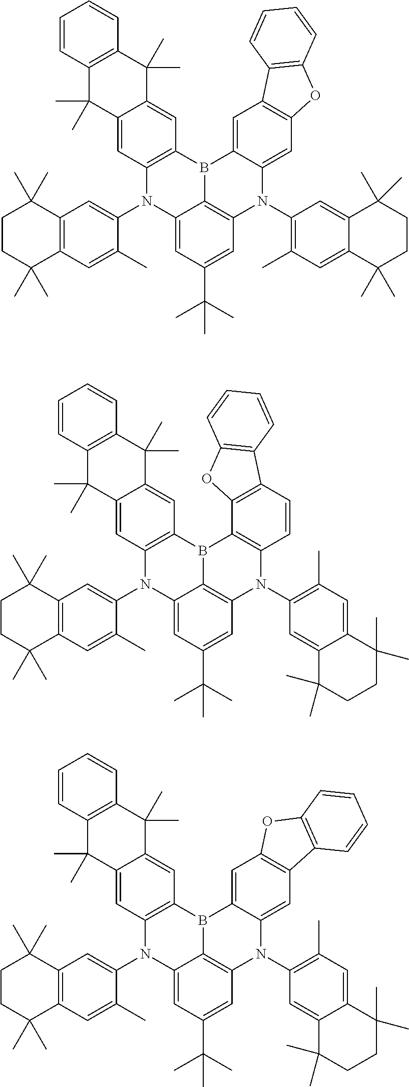 [SMILES: Cc1cc2c(cc1N1c3cc4c(cc3B3c5cc6c(cc5N(c5cc7c(cc5C)C(C)(C)CCC7(C)C)c5cc(C(C)(C)C)cc1c53)oc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5cc6c(cc5C)C(C)(C)CCC6(C)C)c5cc(C(C)(C)C)cc1c53)C(C)(C)c1ccccc1C4(C)C)C(C)(C)CCC2(C)C]

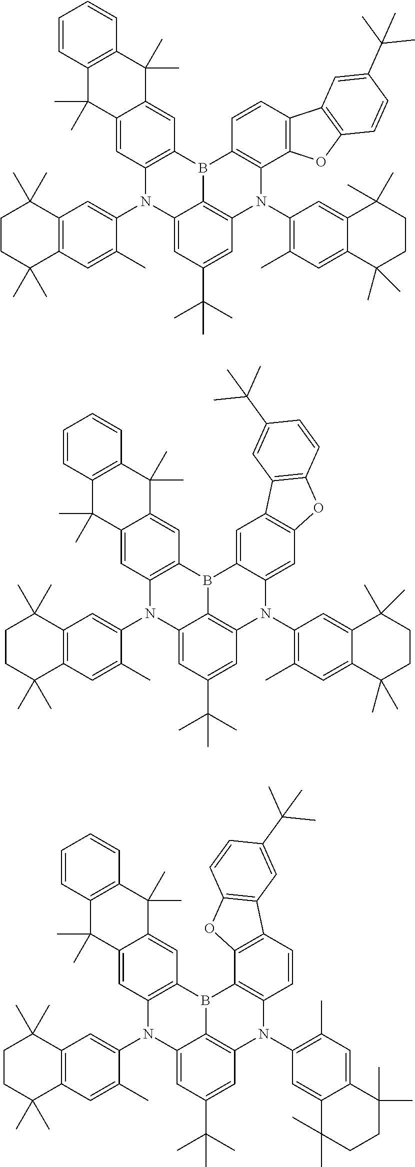

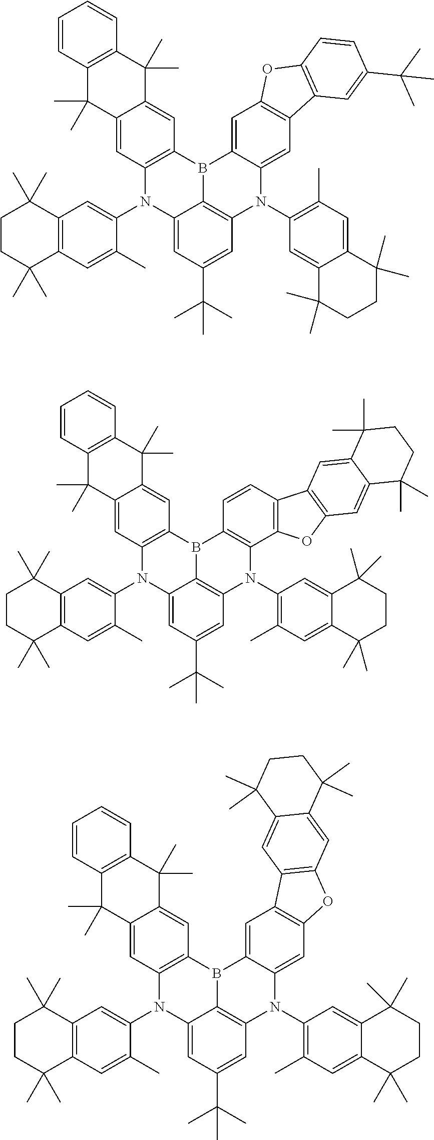 [SMILES: Cc1cc2c(cc1N1c3cc4c(cc3B3c5cc6oc7ccc(C(C)(C)C)cc7c6cc5N(c5cc6c(cc5C)C(C)(C)CCC6(C)C)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5cc6c(cc5C)C(C)(C)CCC6(C)C)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C(C)(C)C)cc1c53)oc1cc3c(cc16)C(C)(C)CCC3(C)C)C(C)(C)c1ccccc1C4(C)C)C(C)(C)CCC2(C)C]

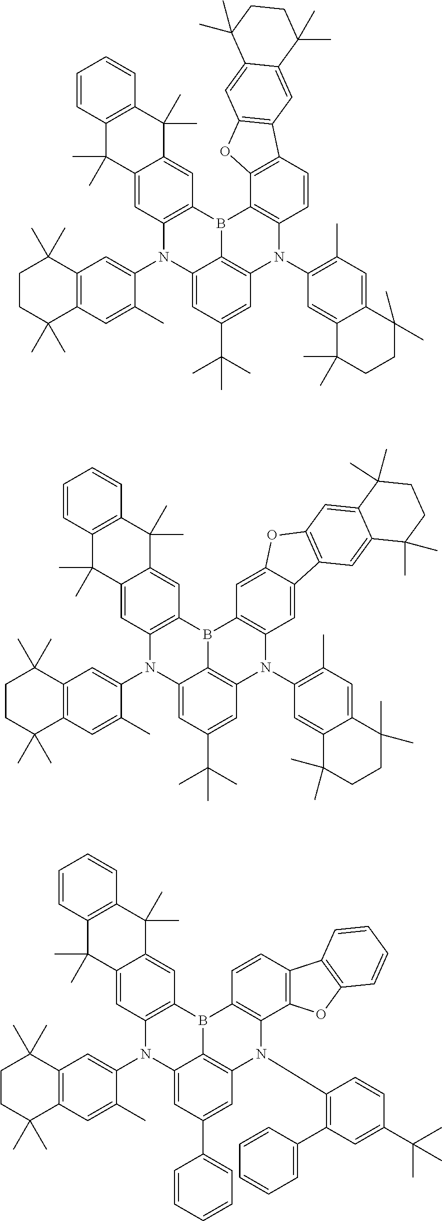 [SMILES: Cc1cc2c(cc1N1c3cc4c(cc3B3c5c1cc(C(C)(C)C)cc5N(c1cc5c(cc1C)C(C)(C)CCC5(C)C)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5cc6c(cc5C)C(C)(C)CCC6(C)C)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C]

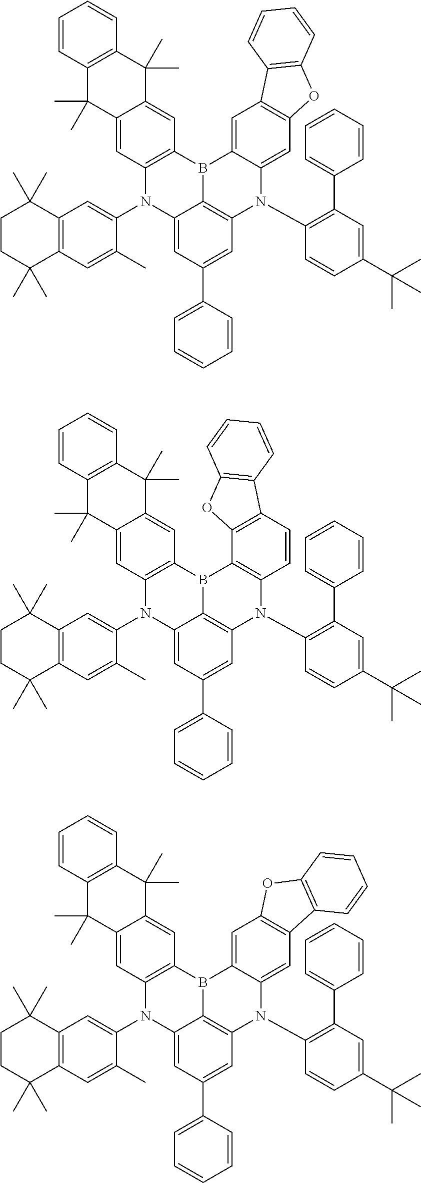 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)oc1ccccc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5ccc(C(C)(C)C)cc5-c5ccccc5)c5cc(-c6ccccc6)cc1c53)C(C)(C)c1ccccc1C4(C)C)C(C)(C)CCC2(C)C]

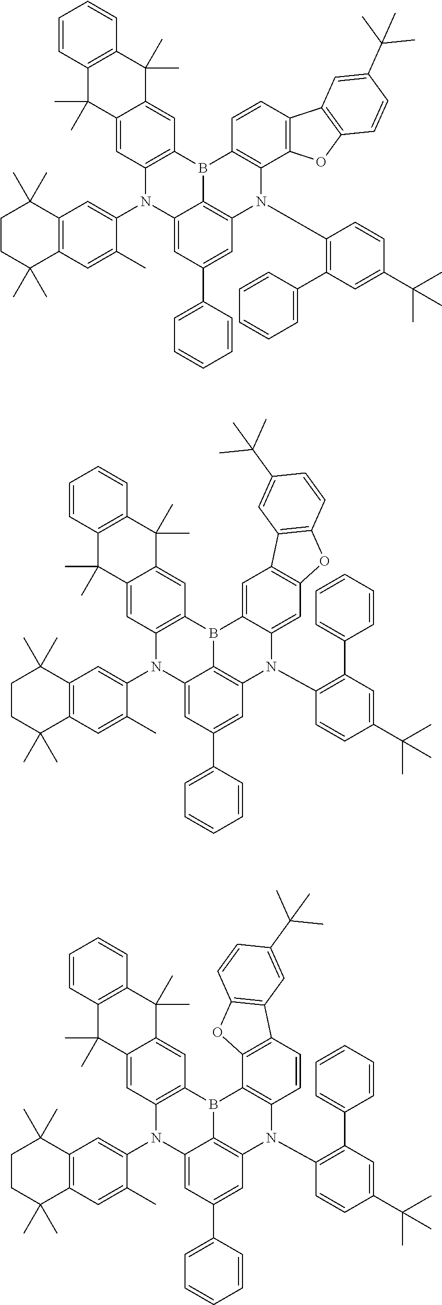 [SMILES: Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(oc6ccc(C(C)(C)C)cc65)c13)C(C)(C)c1ccccc1C4(C)C)C(C)(C)CCC2(C)C]

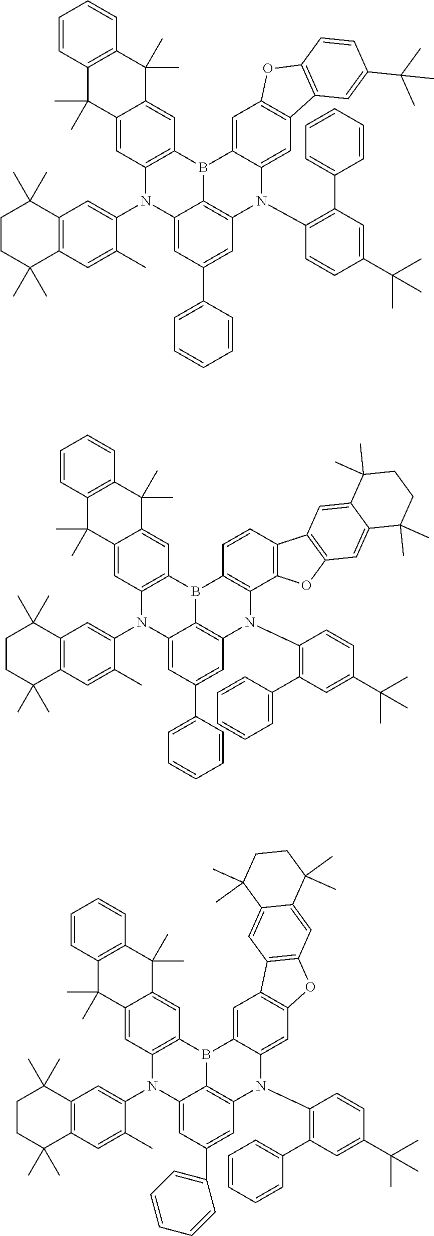 [SMILES: Cc1cc2c(cc1N1c3cc4c(cc3B3c5cc6oc7ccc(C(C)(C)C)cc7c6cc5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)oc1cc3c(cc16)C(C)(C)CCC3(C)C)C(C)(C)c1ccccc1C4(C)C)C(C)(C)CCC2(C)C]

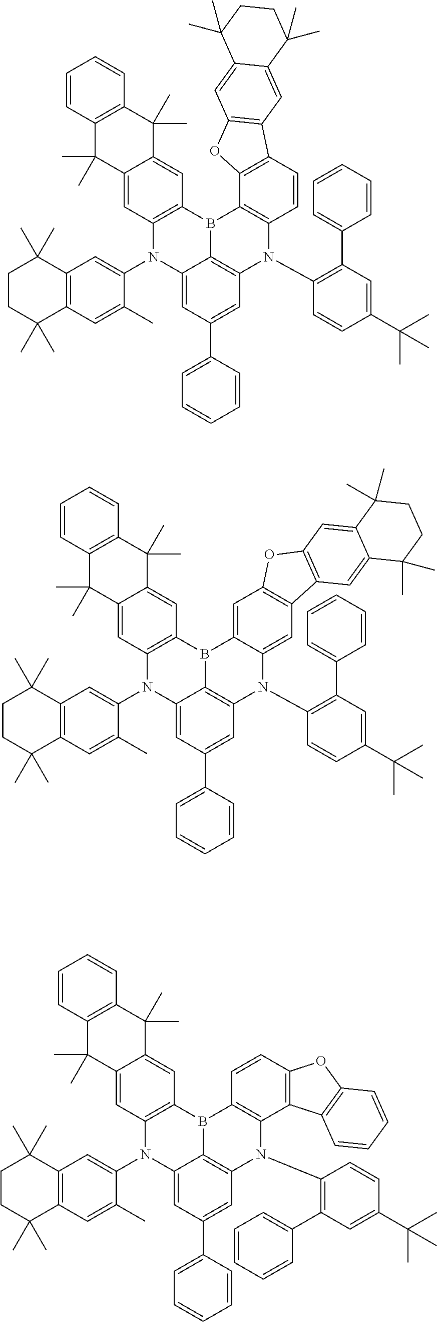 [SMILES: Cc1cc2c(cc1N1c3cc4c(cc3B3c5c1cc(-c1ccccc1)cc5N(c1ccc(C(C)(C)C)cc1-c1ccccc1)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5ccc(C(C)(C)C)cc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7ccccc7c6c5N(c5ccc(C(C)(C)C)cc5-c5ccccc5)c5cc(-c6ccccc6)cc1c53)C(C)(C)c1ccccc1C4(C)C)C(C)(C)CCC2(C)C]

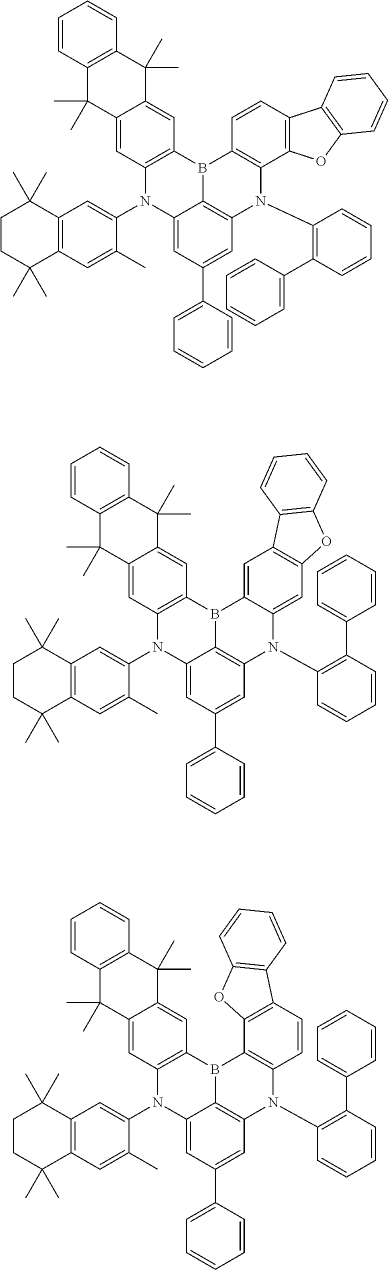 [SMILES: Cc1cc2c(cc1N1c3cc4c(cc3B3c5ccc6c(oc7ccccc76)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)oc1ccccc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(oc6ccccc65)c13)C(C)(C)c1ccccc1C4(C)C)C(C)(C)CCC2(C)C]

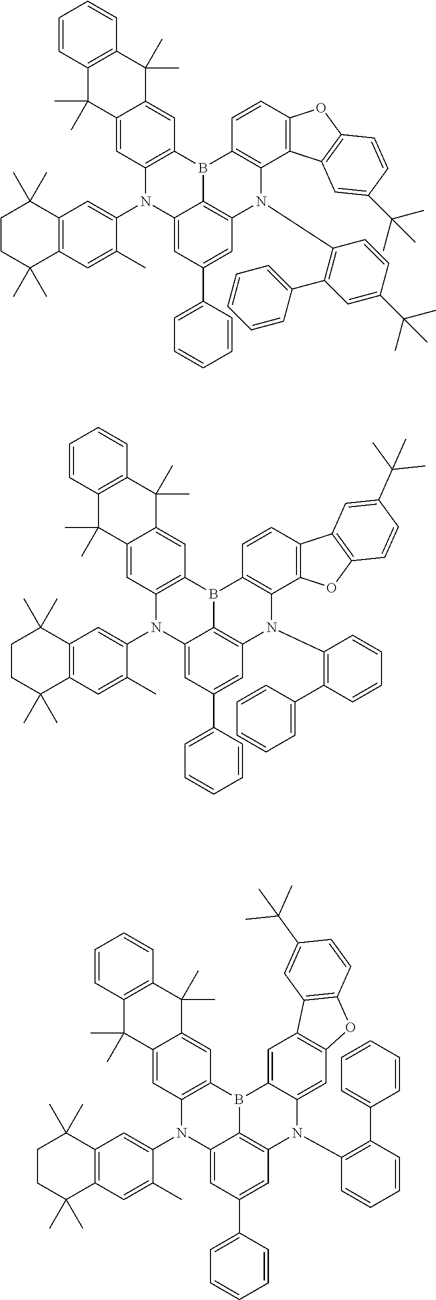 [SMILES: Cc1cc2c(cc1N1c3cc4c(cc3B3c5ccc6oc7ccc(C(C)(C)C)cc7c6c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)oc1ccc(C(C)(C)C)cc16)C(C)(C)c1ccccc1C4(C)C)C(C)(C)CCC2(C)C]

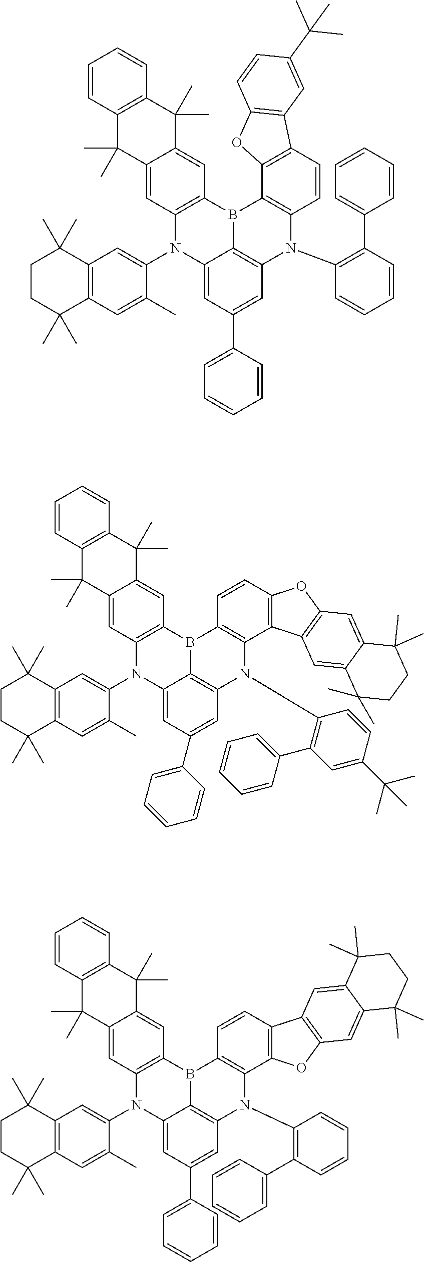 [SMILES: Cc1cc2c(cc1N1c3cc4c(cc3B3c5c1cc(-c1ccccc1)cc5N(c1ccccc1-c1ccccc1)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccc(C(C)(C)C)cc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5-c5ccccc5)c5cc(-c6ccccc6)cc1c53)C(C)(C)c1ccccc1C4(C)C)C(C)(C)CCC2(C)C]

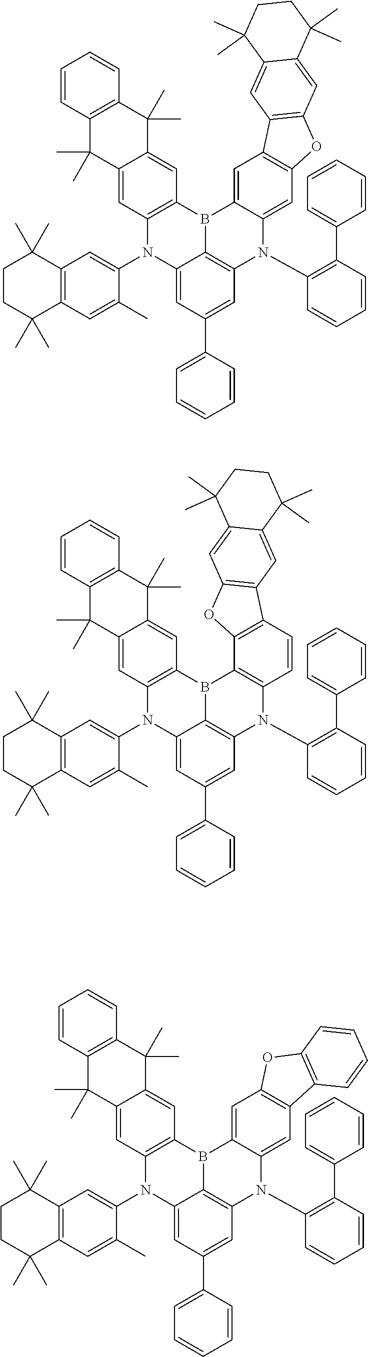 [SMILES: Cc1cc2c(cc1N1c3cc4c(cc3B3c5cc6c(cc5N(c5ccccc5-c5ccccc5)c5cc(-c7ccccc7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5ccccc5-c5ccccc5)c5cc(-c6ccccc6)cc1c53)C(C)(C)c1ccccc1C4(C)C)C(C)(C)CCC2(C)C]

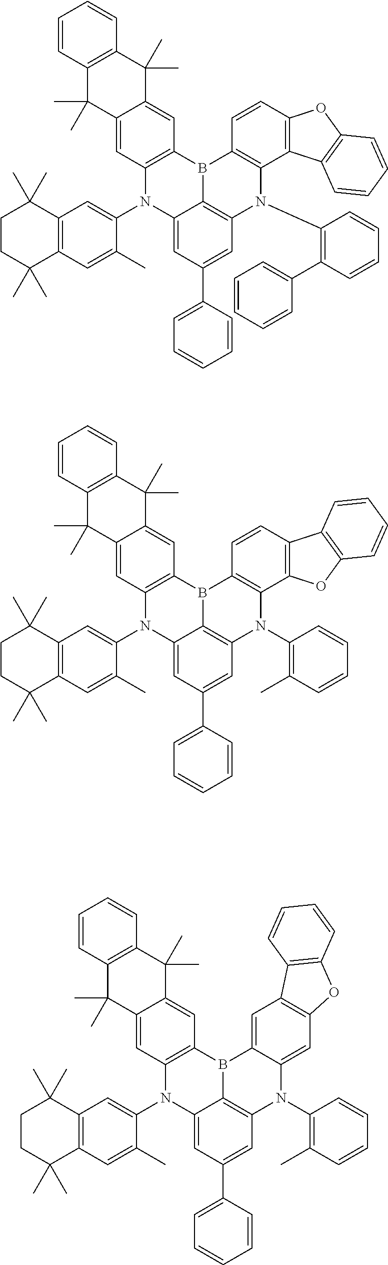 [SMILES: Cc1cc2c(cc1N1c3cc4c(cc3B3c5ccc6oc7ccccc7c6c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5C)c5cc(-c6ccccc6)cc1c53)C(C)(C)c1ccccc1C4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(-c5ccccc5)cc1c32)C(C)(C)c1ccccc1C4(C)C]

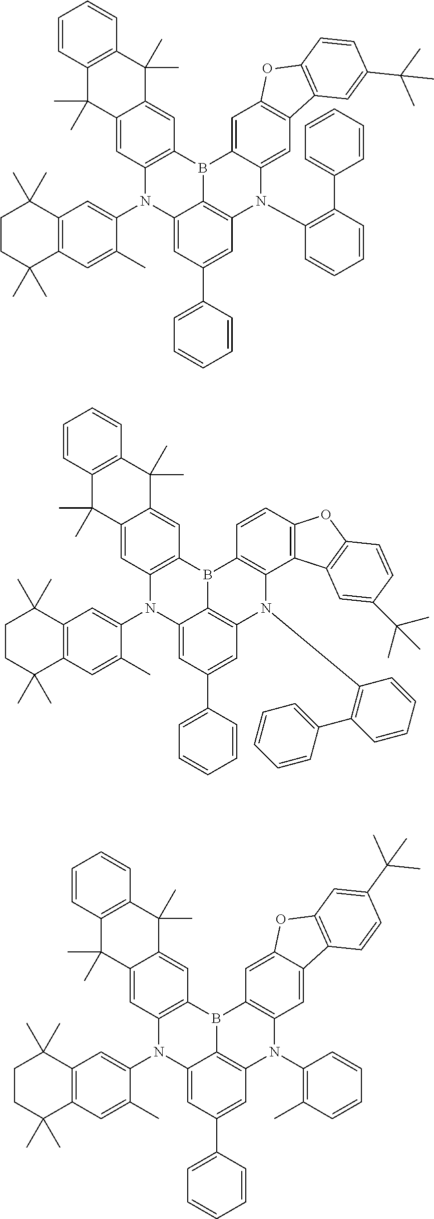 [SMILES: Cc1cc2c(cc1N1c3cc4c(cc3B3c5cc6oc7ccc(C(C)(C)C)cc7c6cc5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6oc7ccc(C(C)(C)C)cc7c6c5N(c5ccccc5-c5ccccc5)c5cc(-c6ccccc6)cc1c53)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)oc1cc(C(C)(C)C)ccc13]

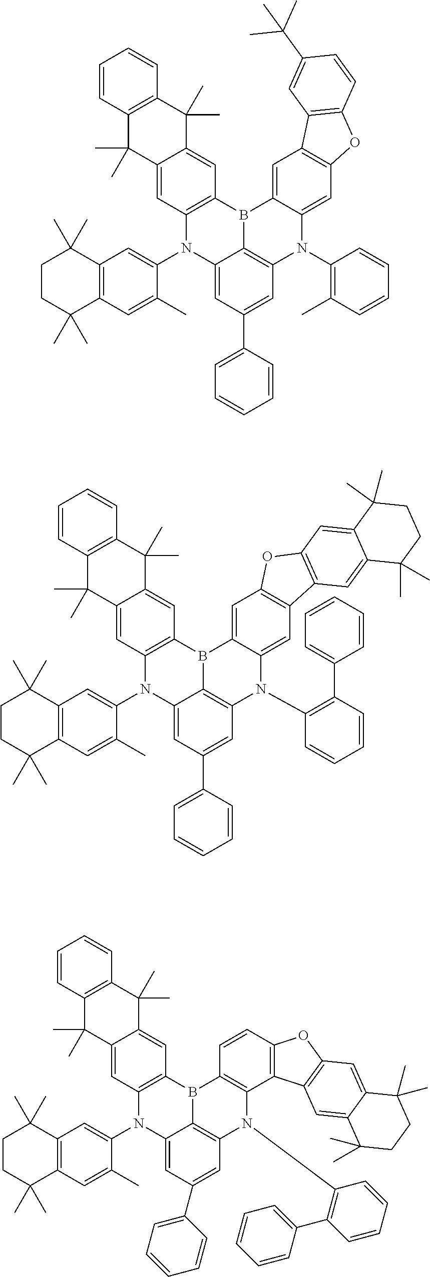 [SMILES: Cc1ccccc1N1c2cc3oc4ccc(C(C)(C)C)cc4c3cc2B2c3cc4c(cc3N(c3cc5c(cc3C)C(C)(C)CCC5(C)C)c3cc(-c5ccccc5)cc1c32)C(C)(C)c1ccccc1C4(C)C ; Cc1cc2c(cc1N1c3cc4c(cc3B3c5cc6oc7cc8c(cc7c6cc5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C]

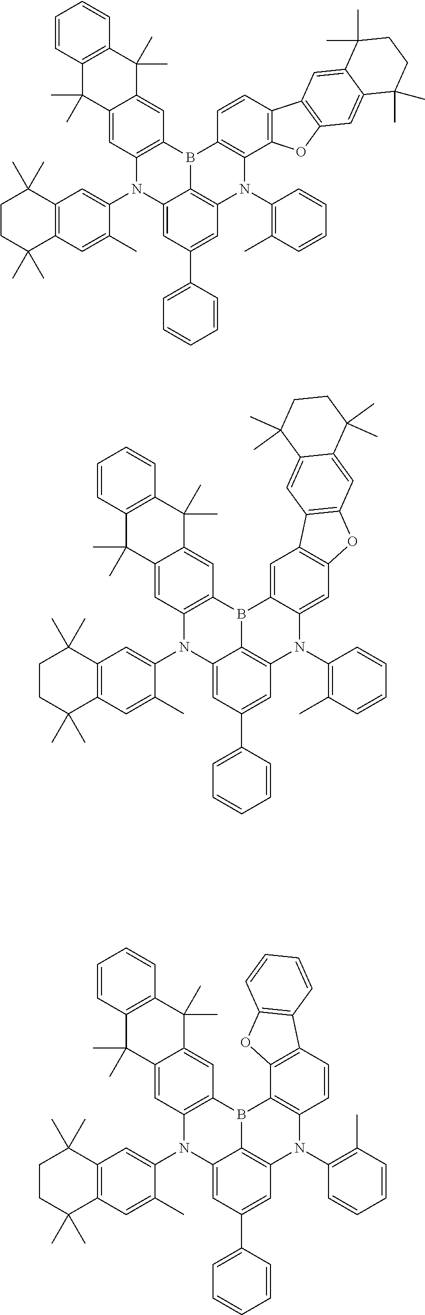 [SMILES: Cc1cc2c(cc1N1c3cc4c(cc3B3c5ccc6c(oc7cc8c(cc76)C(C)(C)CCC8(C)C)c5N(c5ccccc5C)c5cc(-c6ccccc6)cc1c53)C(C)(C)c1ccccc1C4(C)C)C(C)(C)CCC2(C)C ; Cc1ccccc1N1c2cc3oc4cc5c(cc4c3cc2B2c3cc4c(cc3N(c3cc6c(cc3C)C(C)(C)CCC6(C)C)c3cc(-c6ccccc6)cc1c32)C(C)(C)c1ccccc1C4(C)C)C(C)(C)CCC5(C)C ; Cc1cc2c(cc1N1c3cc4c(cc3B3c5c1cc(-c1ccccc1)cc5N(c1ccccc1C)c1ccc5c(oc6ccccc65)c13)C(C)(C)c1ccccc1C4(C)C)C(C)(C)CCC2(C)C]

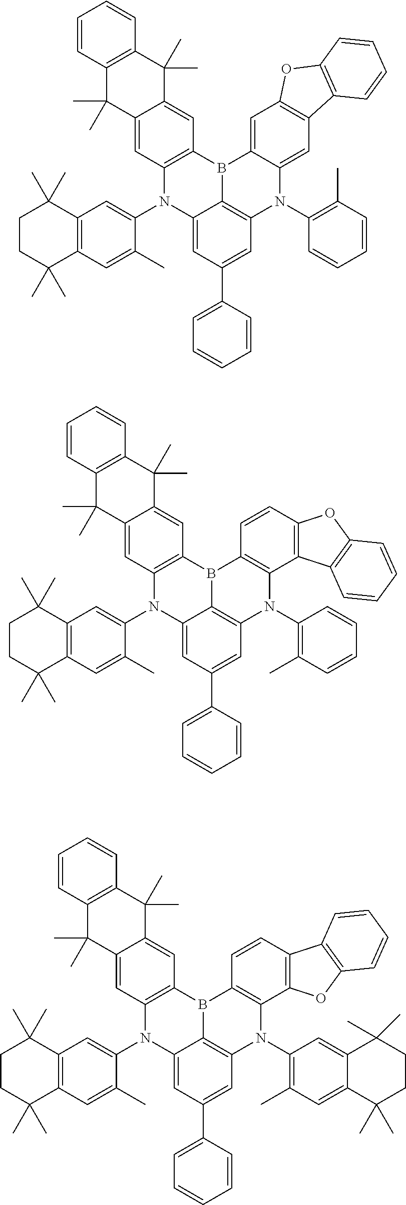 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)oc1ccccc13 ; Cc1cc2c(cc1N1c3cc4c(cc3B3c5ccc6oc7ccccc7c6c5N(c5ccccc5C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C]

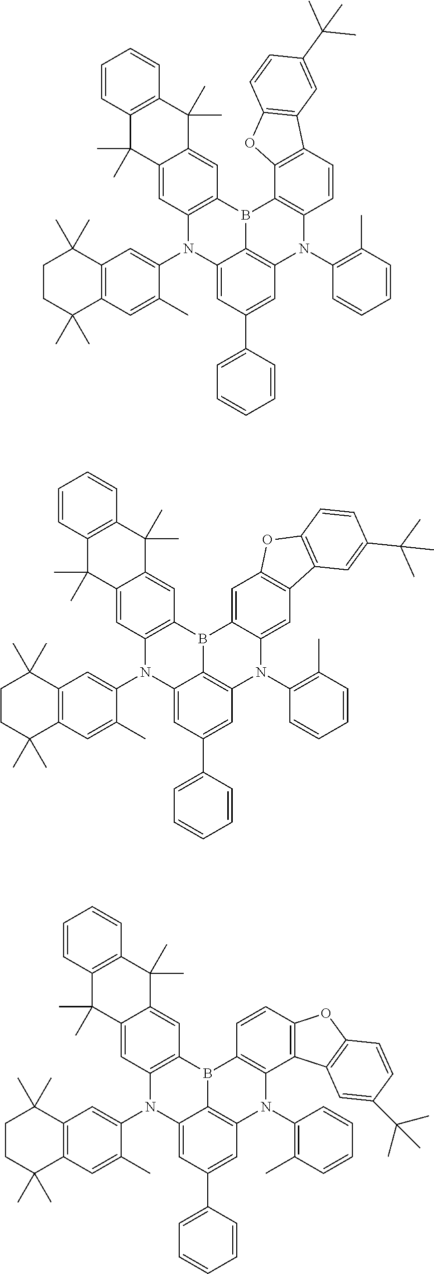 [SMILES: Cc1cc2c(cc1N1c3cc4c(cc3B3c5c1cc(-c1ccccc1)cc5N(c1ccccc1C)c1ccc5c(oc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)oc1ccc(C(C)(C)C)cc13 ; Cc1cc2c(cc1N1c3cc4c(cc3B3c5ccc6oc7ccc(C(C)(C)C)cc7c6c5N(c5ccccc5C)c5cc(-c6ccccc6)cc1c53)C(C)(C)c1ccccc1C4(C)C)C(C)(C)CCC2(C)C]

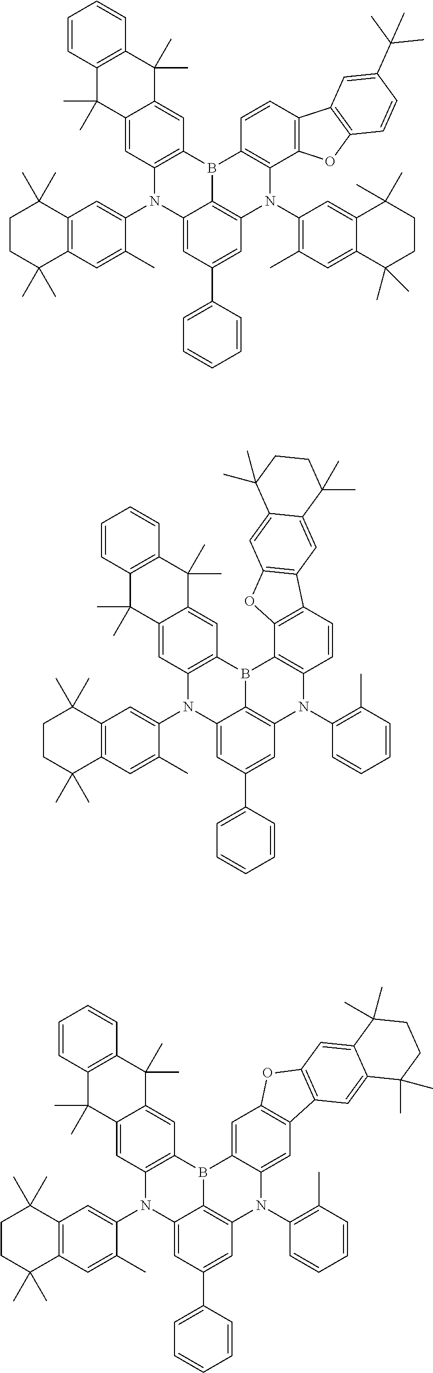 [SMILES: Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1C)c1ccc5c(oc6cc7c(cc65)C(C)(C)CCC7(C)C)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)oc1cc2c(cc13)C(C)(C)CCC2(C)C]

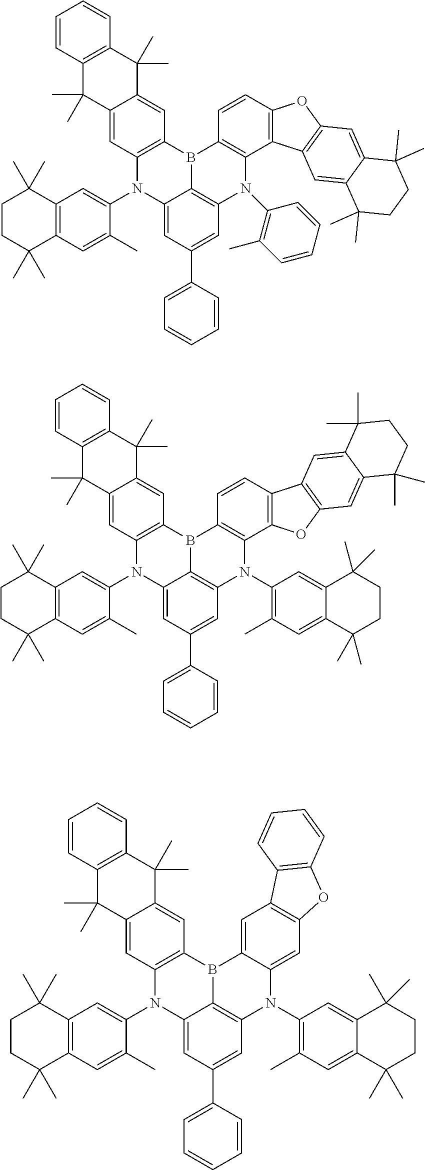 [SMILES: Cc1cc2c(cc1N1c3cc4c(cc3B3c5ccc6oc7cc8c(cc7c6c5N(c5ccccc5C)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)oc1ccccc16)C(C)(C)c1ccccc1C4(C)C)C(C)(C)CCC2(C)C]

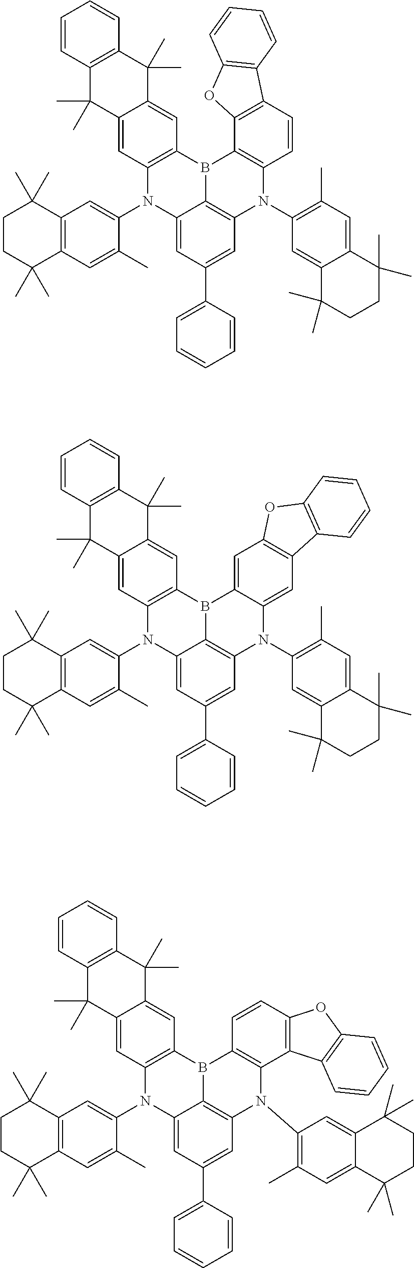 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C]

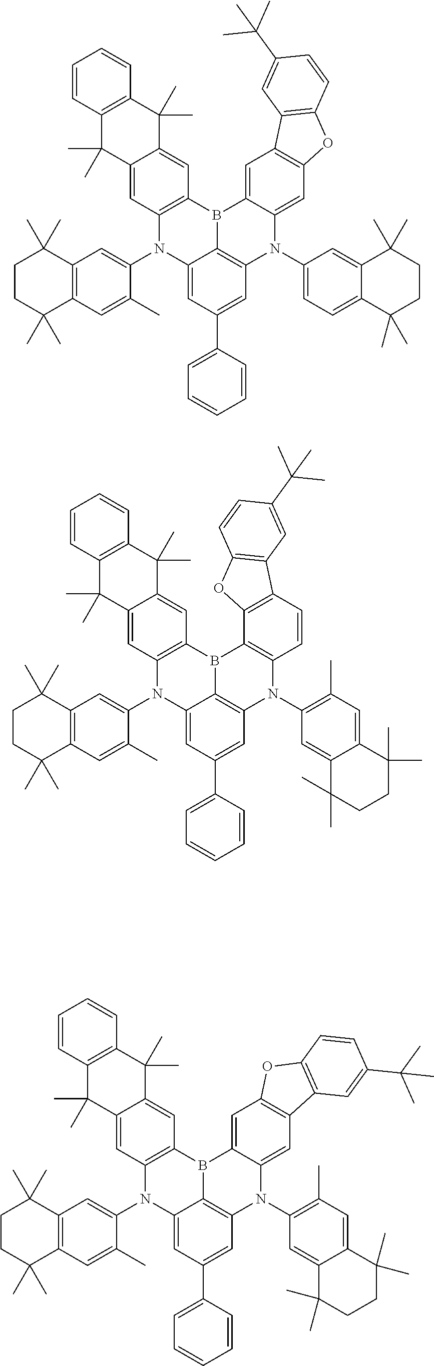 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6oc7ccc(C(C)(C)C)cc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C]

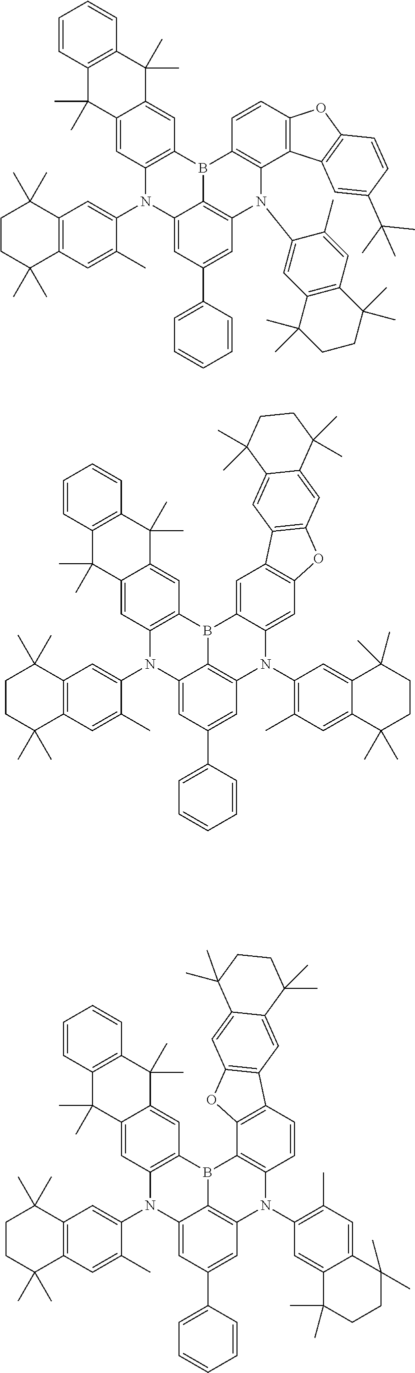 [SMILES: Cc1cc2c(cc1N1c3cc4c(cc3B3c5ccc6oc7ccc(C(C)(C)C)cc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(oc6cc7c(cc65)C(C)(C)CCC7(C)C)c13)C(C)(C)c1ccccc1C4(C)C)C(C)(C)CCC2(C)C]

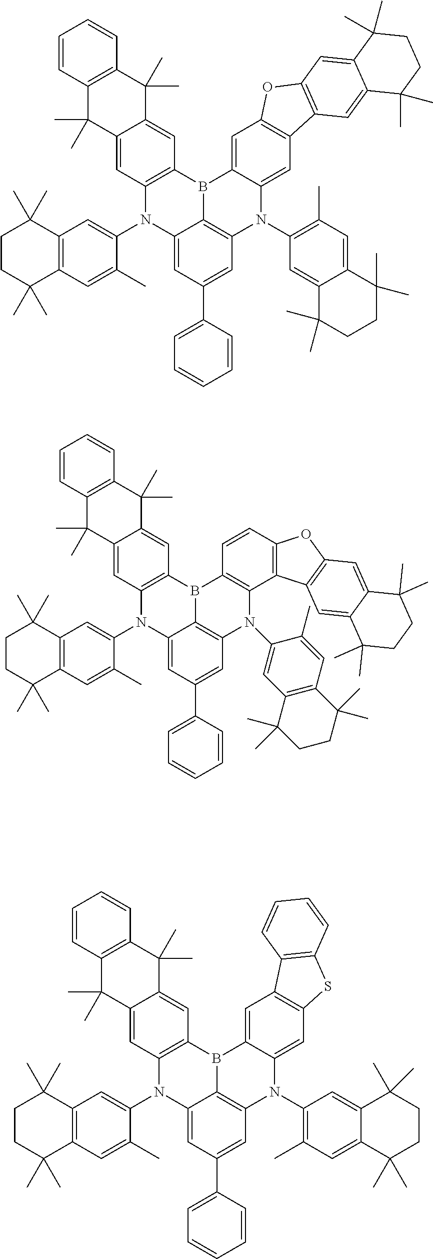 [SMILES: Cc1cc2c(cc1N1c3cc4c(cc3B3c5cc6oc7cc8c(cc7c6cc5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)sc1ccccc16)C(C)(C)c1ccccc1C4(C)C)C(C)(C)CCC2(C)C]

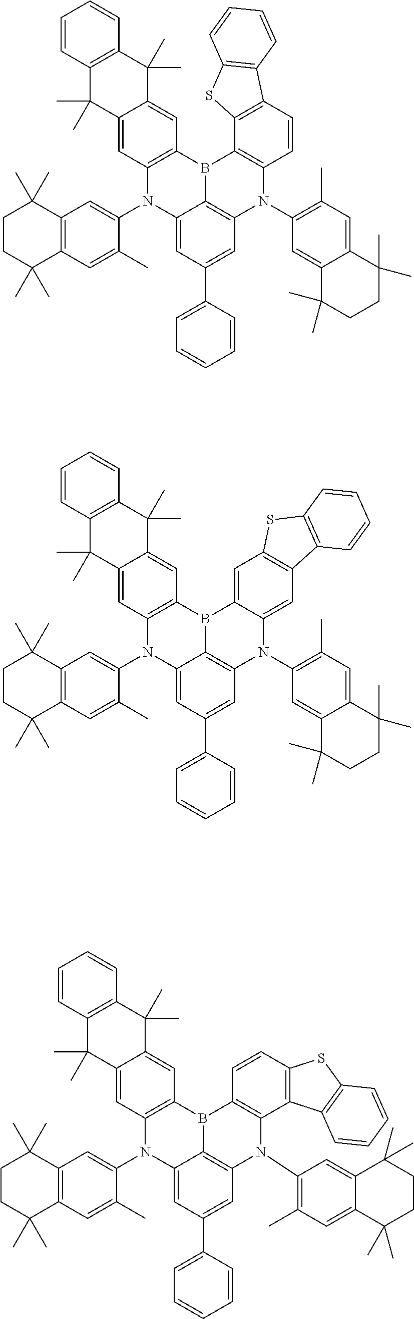 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(sc6ccccc65)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6sc7ccccc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C]

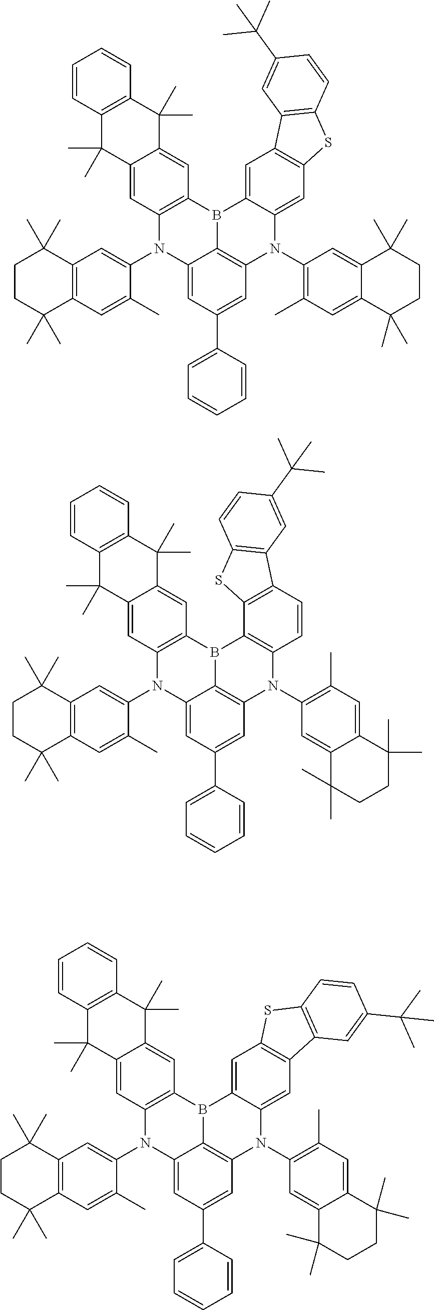 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6sc7ccc(C(C)(C)C)cc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C]

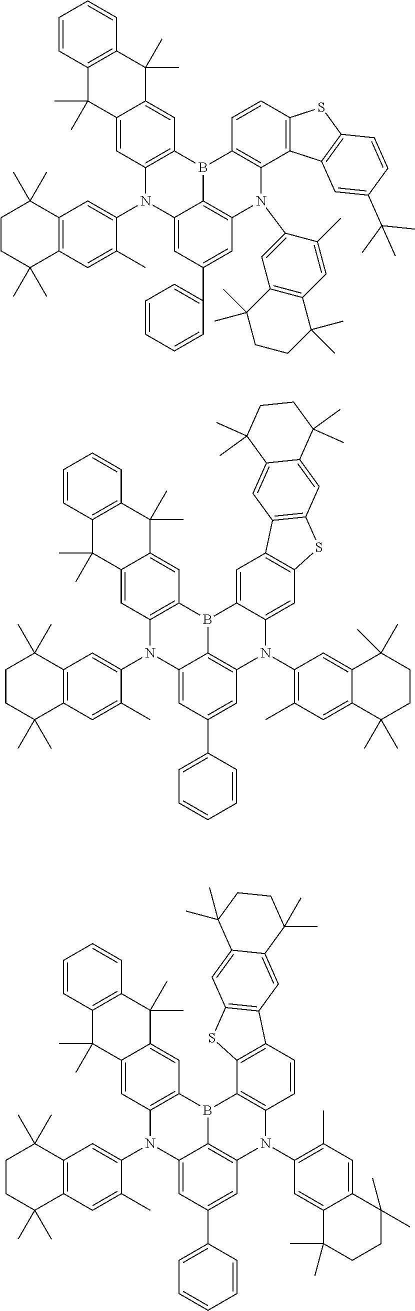 [SMILES: Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(sc6cc7c(cc65)C(C)(C)CCC7(C)C)c13)C(C)(C)c1ccccc1C4(C)C)C(C)(C)CCC2(C)C]

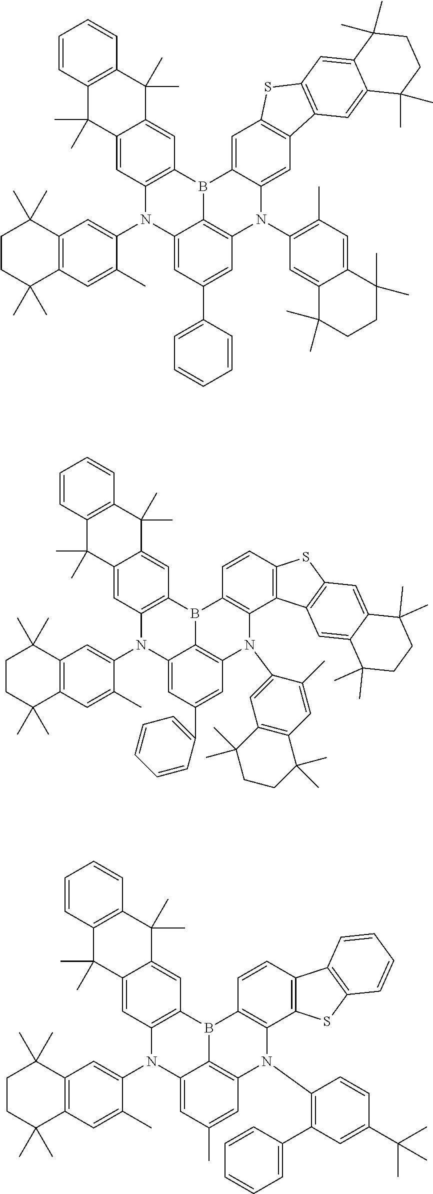 [SMILES: Cc1cc2c(cc1N1c3cc4c(cc3B3c5cc6sc7cc8c(cc7c6cc5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C ; Cc1cc2c3c(c1)N(c1ccc(C(C)(C)C)cc1-c1ccccc1)c1c(ccc4c1sc1ccccc14)B3c1cc3c(cc1N2c1cc2c(cc1C)C(C)(C)CCC2(C)C)C(C)(C)c1ccccc1C3(C)C]

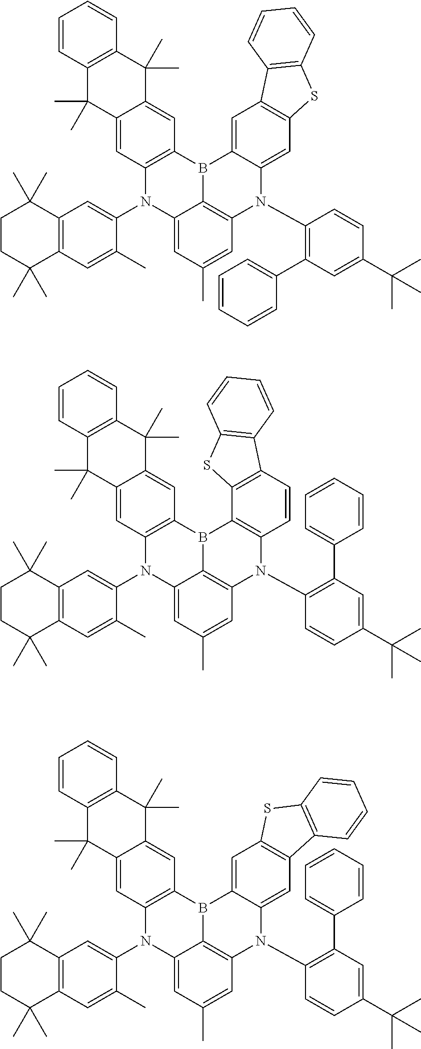 [SMILES: Cc1cc2c3c(c1)N(c1ccc(C(C)(C)C)cc1-c1ccccc1)c1cc4sc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1ccc4c(sc5ccccc54)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1ccccc14]

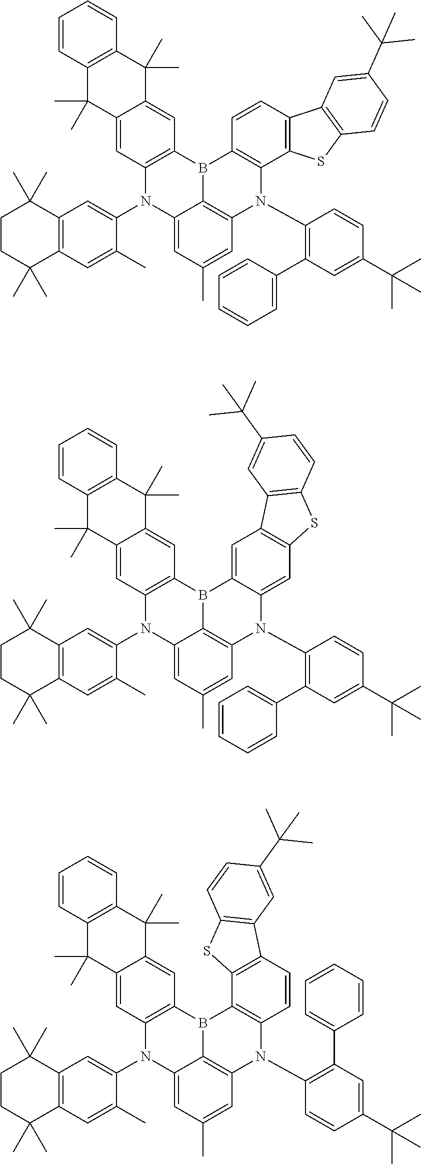 [SMILES: Cc1cc2c3c(c1)N(c1ccc(C(C)(C)C)cc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4sc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C]

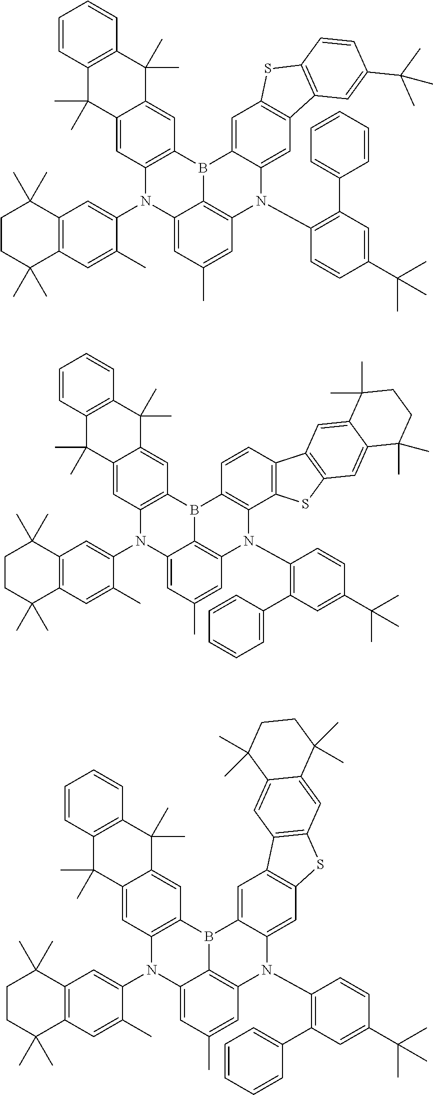 [SMILES: Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14 ; Cc1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4sc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

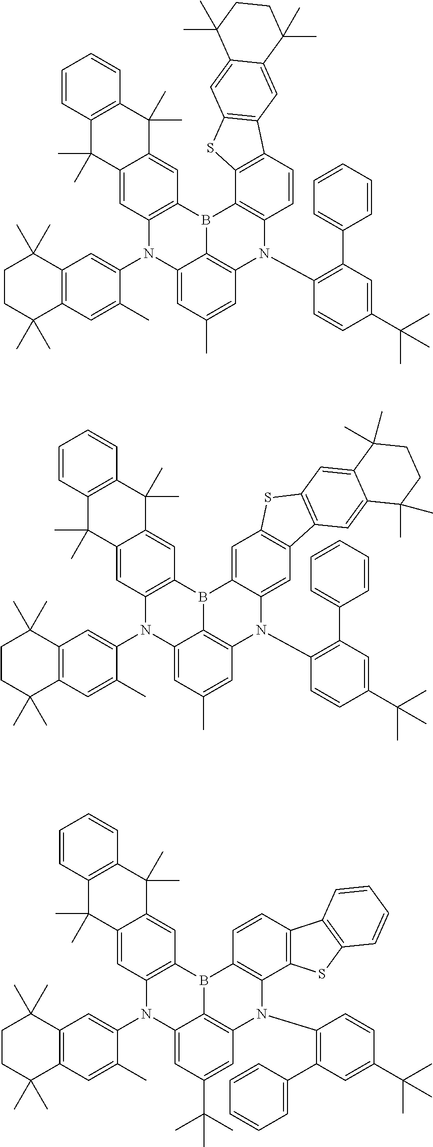 [SMILES: Cc1cc2c3c(c1)N(c1ccc(C(C)(C)C)cc1-c1ccccc1)c1ccc4c(sc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1cc2c(cc14)C(C)(C)CCC2(C)C ; Cc1cc2c(cc1N1c3cc4c(cc3B3c5ccc6c(sc7ccccc76)c5N(c5ccc(C(C)(C)C)cc5-c5ccccc5)c5cc(C(C)(C)C)cc1c53)C(C)(C)c1ccccc1C4(C)C)C(C)(C)CCC2(C)C]

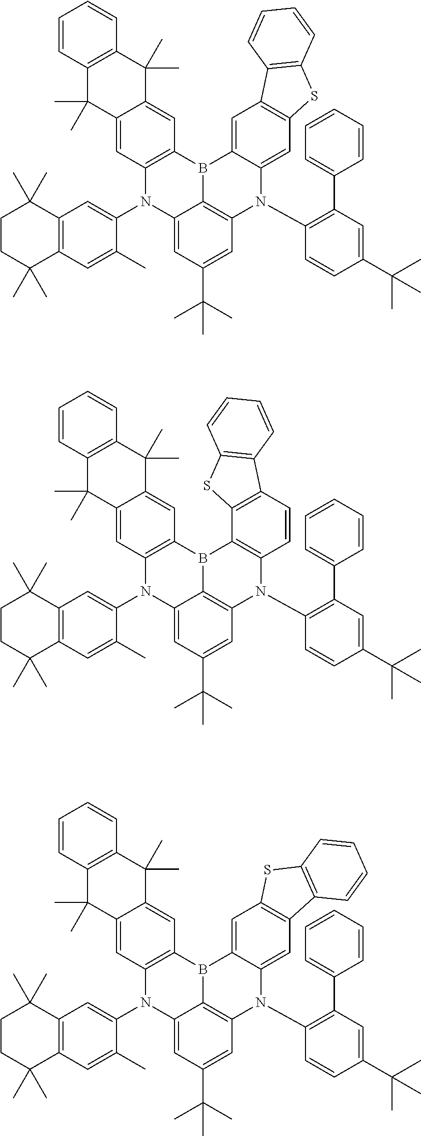 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)sc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C]

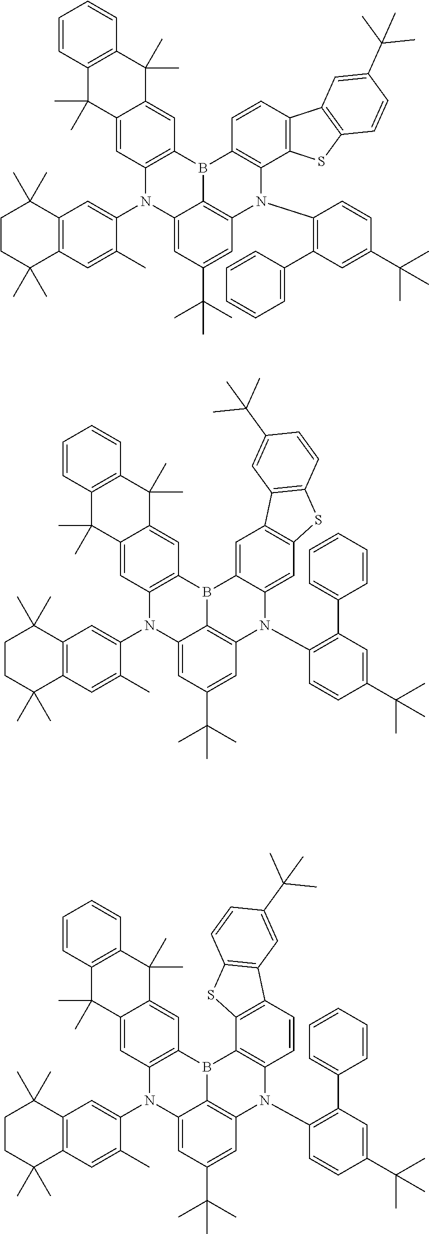 [SMILES: Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)CCC2(C)C]

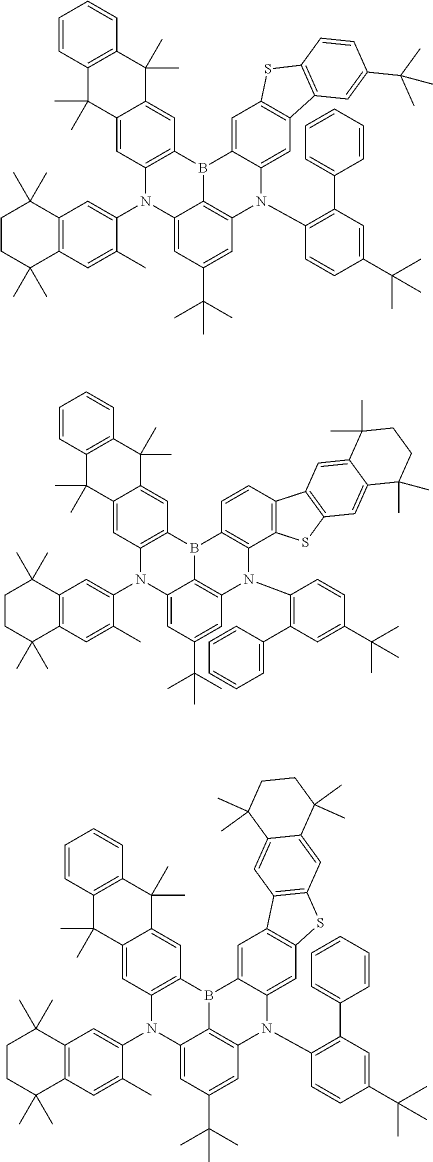 [SMILES: Cc1cc2c(cc1N1c3cc4c(cc3B3c5cc6sc7ccc(C(C)(C)C)cc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)sc1cc3c(cc16)C(C)(C)CCC3(C)C)C(C)(C)c1ccccc1C4(C)C)C(C)(C)CCC2(C)C]

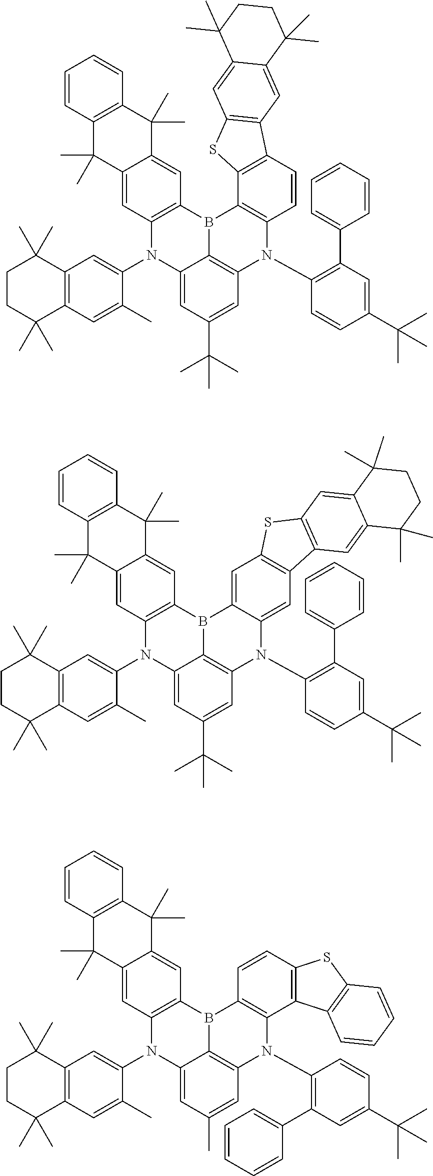 [SMILES: Cc1cc2c(cc1N1c3cc4c(cc3B3c5c1cc(C(C)(C)C)cc5N(c1ccc(C(C)(C)C)cc1-c1ccccc1)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c3c(c1)N(c1ccc(C(C)(C)C)cc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C]

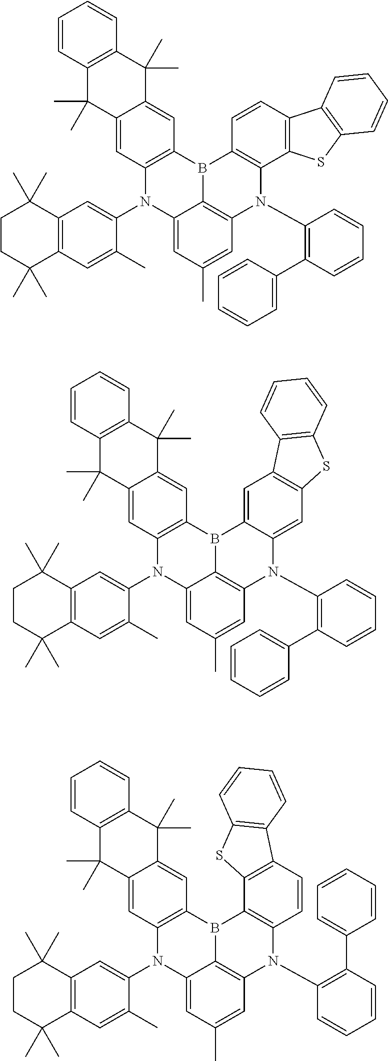 [SMILES: Cc1cc2c3c(c1)N(c1ccccc1-c1ccccc1)c1c(ccc4c1sc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4sc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1ccc4c(sc5ccccc54)c1B3c1cc3c(cc1N2c1cc2c(cc1C)C(C)(C)CCC2(C)C)C(C)(C)c1ccccc1C3(C)C]

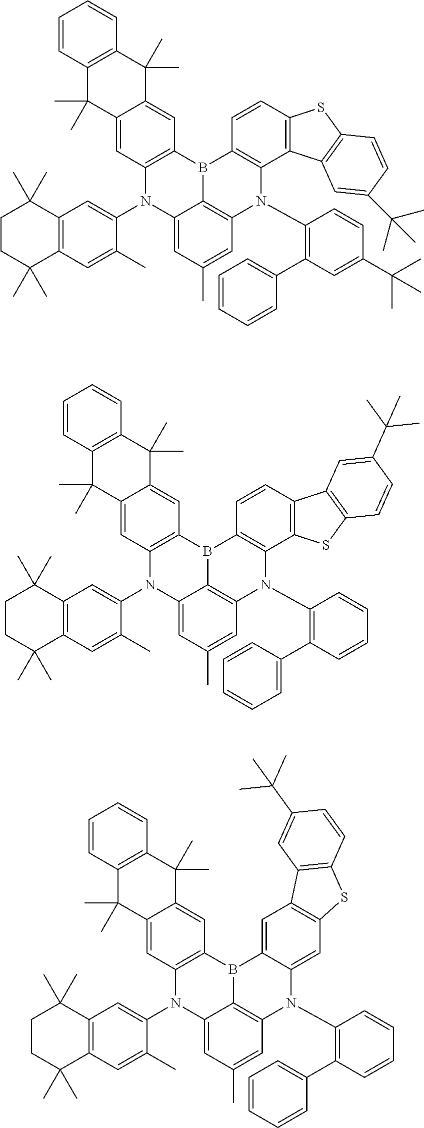 [SMILES: Cc1cc2c3c(c1)N(c1ccc(C(C)(C)C)cc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4sc5ccc(C(C)(C)C)cc5c4cc1B3c1cc3c(cc1N2c1cc2c(cc1C)C(C)(C)CCC2(C)C)C(C)(C)c1ccccc1C3(C)C]

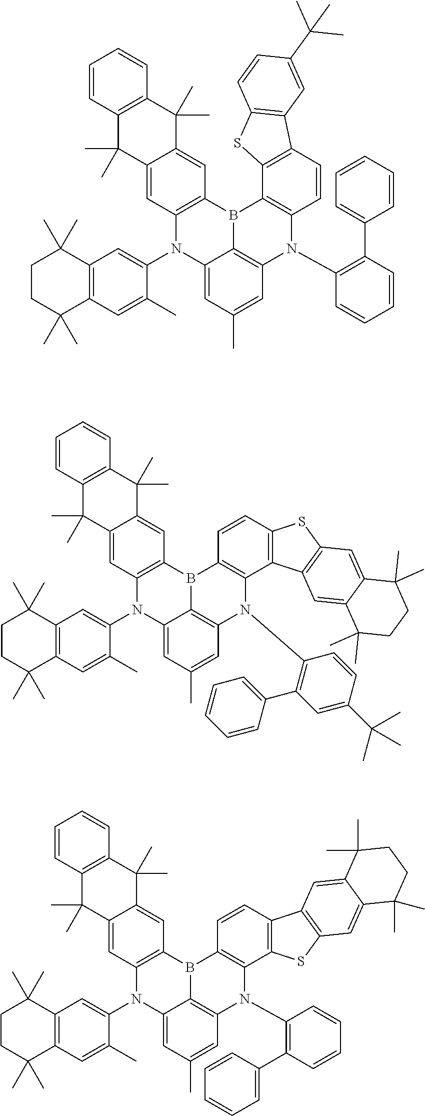 [SMILES: Cc1cc2c3c(c1)N(c1ccccc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

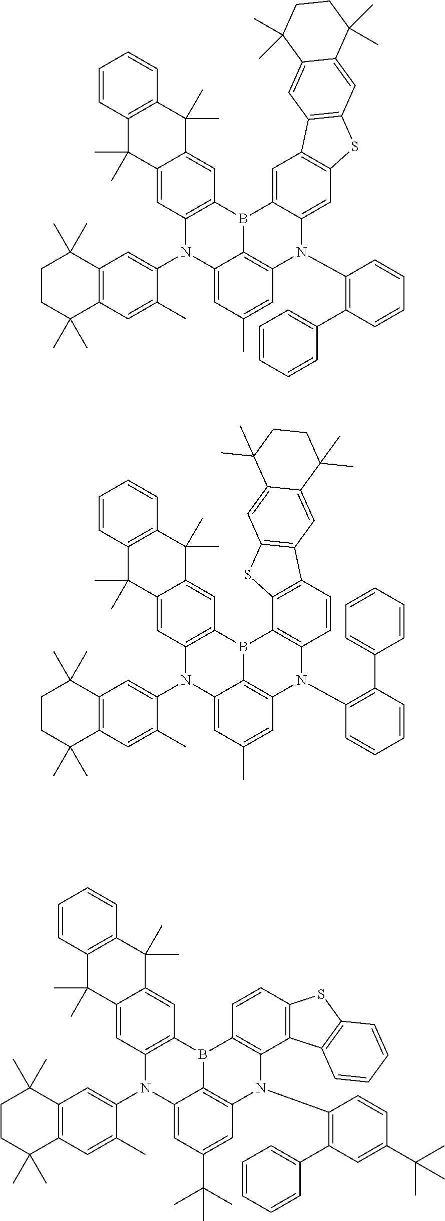 [SMILES: Cc1cc2c3c(c1)N(c1ccccc1-c1ccccc1)c1cc4sc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1cc2c3c(c1)N(c1ccccc1-c1ccccc1)c1ccc4c(sc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1cc2c(cc1N1c3cc4c(cc3B3c5ccc6sc7ccccc7c6c5N(c5ccc(C(C)(C)C)cc5-c5ccccc5)c5cc(C(C)(C)C)cc1c53)C(C)(C)c1ccccc1C4(C)C)C(C)(C)CCC2(C)C]

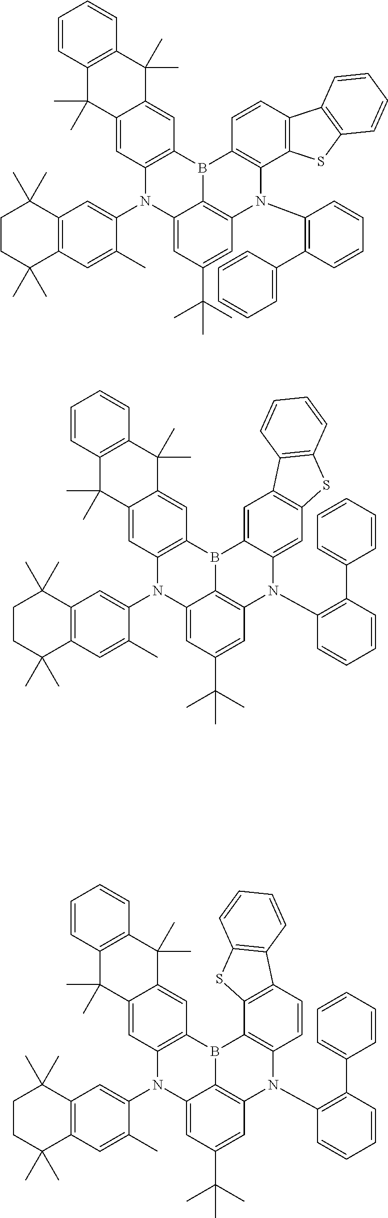 [SMILES: Cc1cc2c(cc1N1c3cc4c(cc3B3c5ccc6c(sc7ccccc76)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)sc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(sc6ccccc65)c13)C(C)(C)c1ccccc1C4(C)C)C(C)(C)CCC2(C)C]

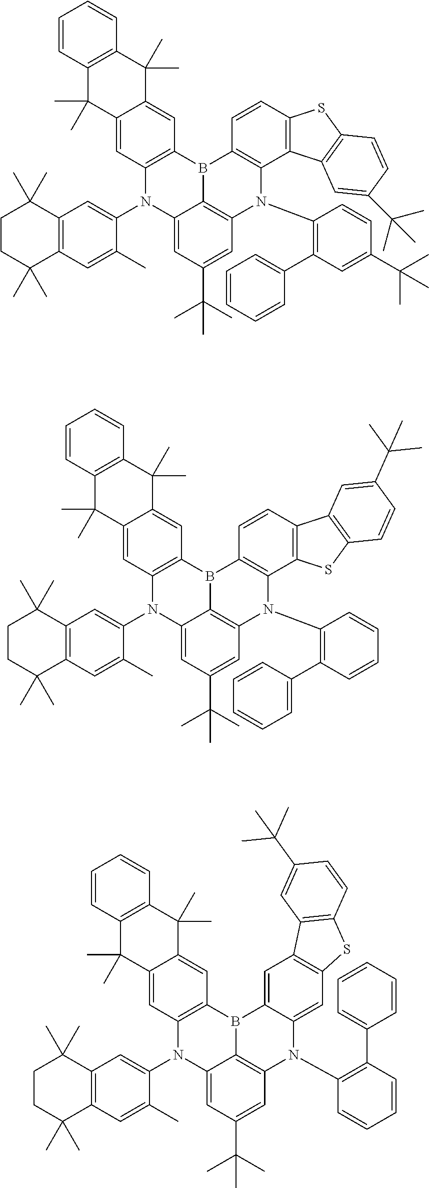 [SMILES: Cc1cc2c(cc1N1c3cc4c(cc3B3c5ccc6sc7ccc(C(C)(C)C)cc7c6c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)sc1ccc(C(C)(C)C)cc16)C(C)(C)c1ccccc1C4(C)C)C(C)(C)CCC2(C)C]

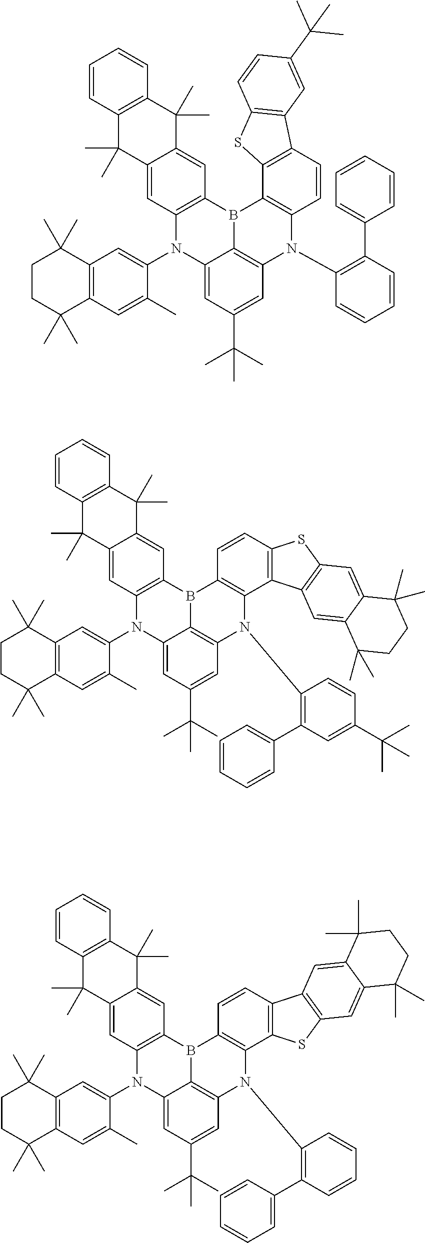 [SMILES: Cc1cc2c(cc1N1c3cc4c(cc3B3c5c1cc(C(C)(C)C)cc5N(c1ccccc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5-c5ccccc5)c5cc(C(C)(C)C)cc1c53)C(C)(C)c1ccccc1C4(C)C)C(C)(C)CCC2(C)C]

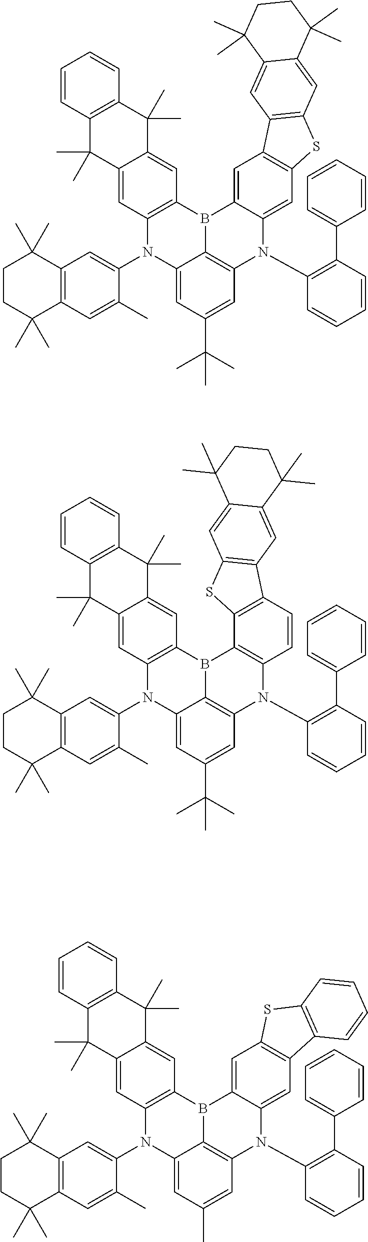 [SMILES: Cc1cc2c(cc1N1c3cc4c(cc3B3c5cc6c(cc5N(c5ccccc5-c5ccccc5)c5cc(C(C)(C)C)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(sc6cc7c(cc65)C(C)(C)CCC7(C)C)c13)C(C)(C)c1ccccc1C4(C)C)C(C)(C)CCC2(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccccc14]

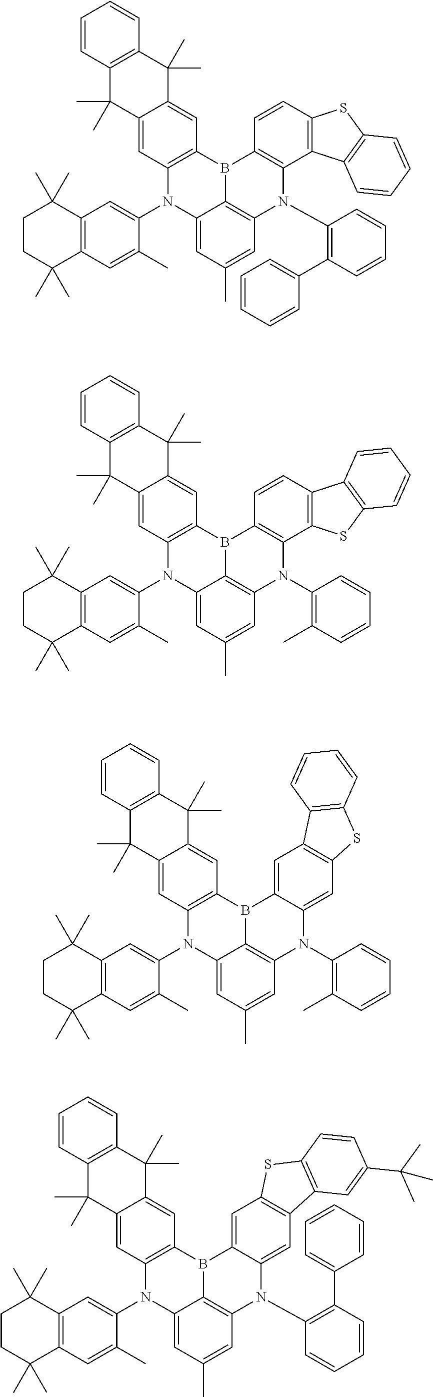 [SMILES: Cc1cc2c3c(c1)N(c1ccccc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4sc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14]

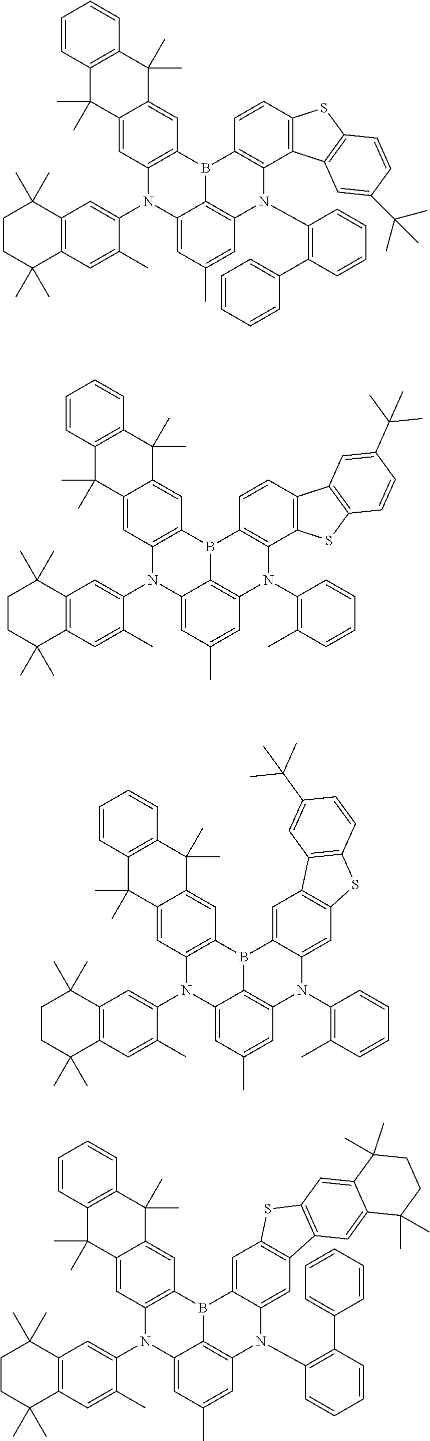

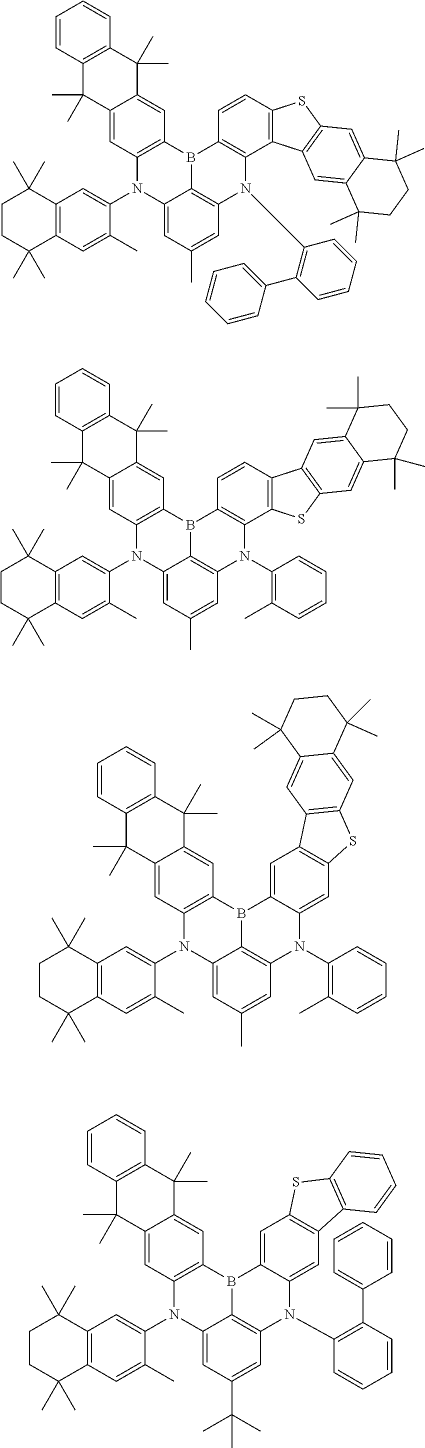

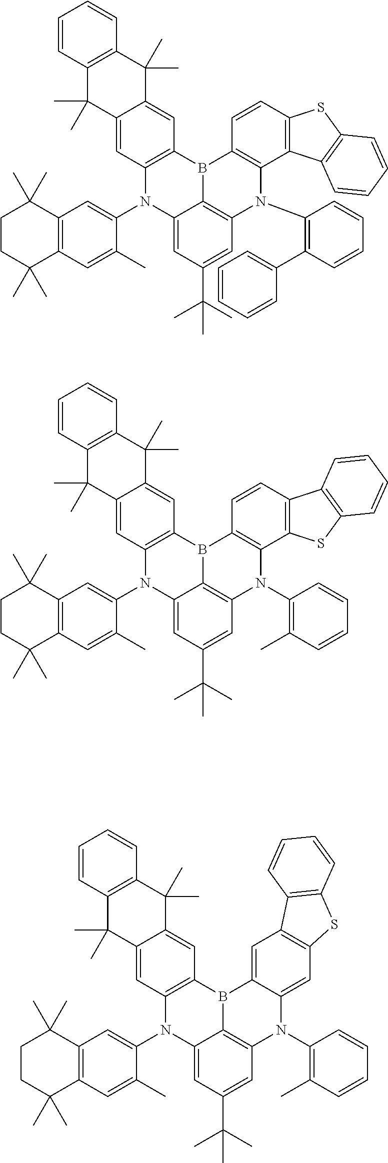 [SMILES: Cc1cc2c(cc1N1c3cc4c(cc3B3c5ccc6sc7ccccc7c6c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5C)c5cc(C(C)(C)C)cc1c53)C(C)(C)c1ccccc1C4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(C(C)(C)C)cc1c32)C(C)(C)c1ccccc1C4(C)C]

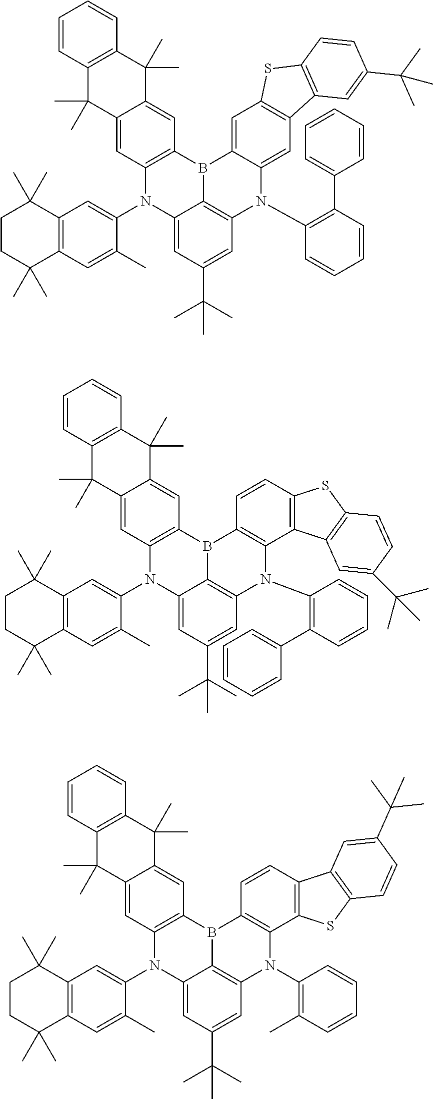 [SMILES: Cc1cc2c(cc1N1c3cc4c(cc3B3c5cc6sc7ccc(C(C)(C)C)cc7c6cc5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(C(C)(C)C)cc1c53)C(C)(C)c1ccccc1C4(C)C)C(C)(C)CCC2(C)C]

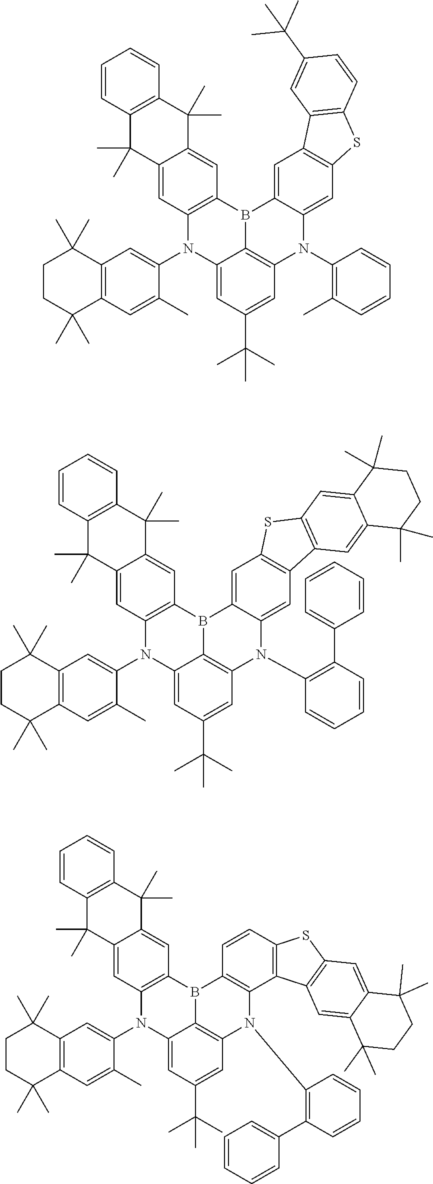 [SMILES: Cc1ccccc1N1c2cc3sc4ccc(C(C)(C)C)cc4c3cc2B2c3cc4c(cc3N(c3cc5c(cc3C)C(C)(C)CCC5(C)C)c3cc(C(C)(C)C)cc1c32)C(C)(C)c1ccccc1C4(C)C ; Cc1cc2c(cc1N1c3cc4c(cc3B3c5cc6sc7cc8c(cc7c6cc5N(c5ccccc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(C(C)(C)C)cc1c53)C(C)(C)CCC8(C)C)C(C)(C)c1ccccc1C4(C)C)C(C)(C)CCC2(C)C]

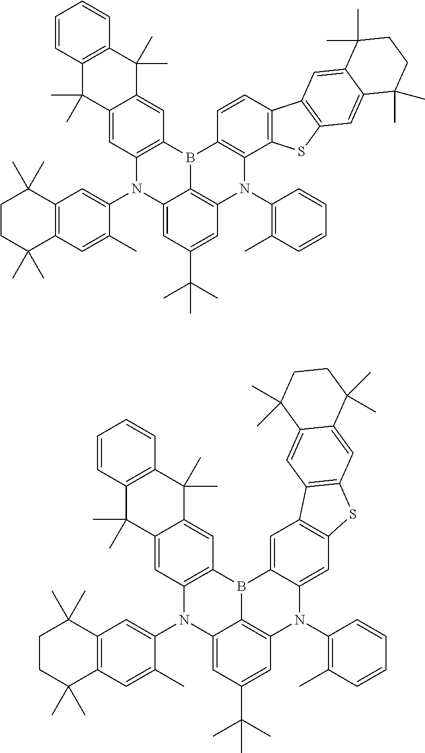 [SMILES: Cc1cc2c(cc1N1c3cc4c(cc3B3c5ccc6c(sc7cc8c(cc76)C(C)(C)CCC8(C)C)c5N(c5ccccc5C)c5cc(C(C)(C)C)cc1c53)C(C)(C)c1ccccc1C4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(C(C)(C)C)cc1c32)C(C)(C)c1ccccc1C4(C)C)C(C)(C)CCC5(C)C]

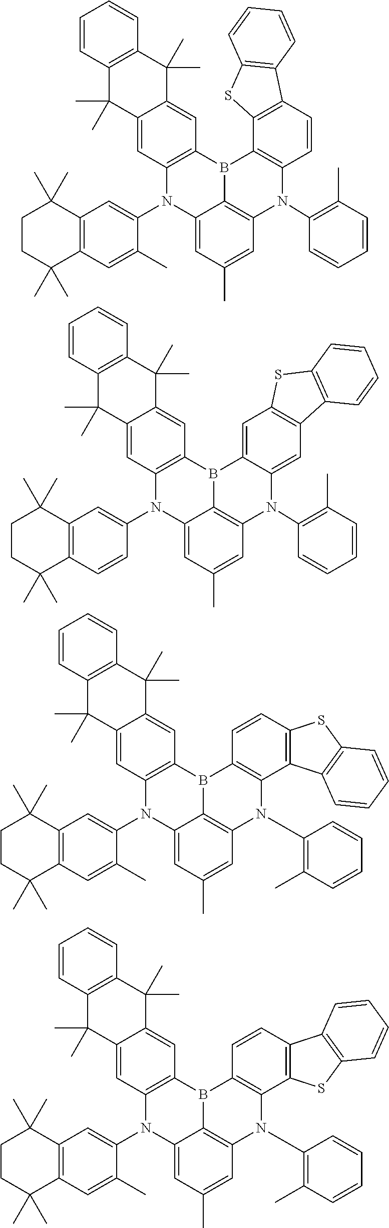

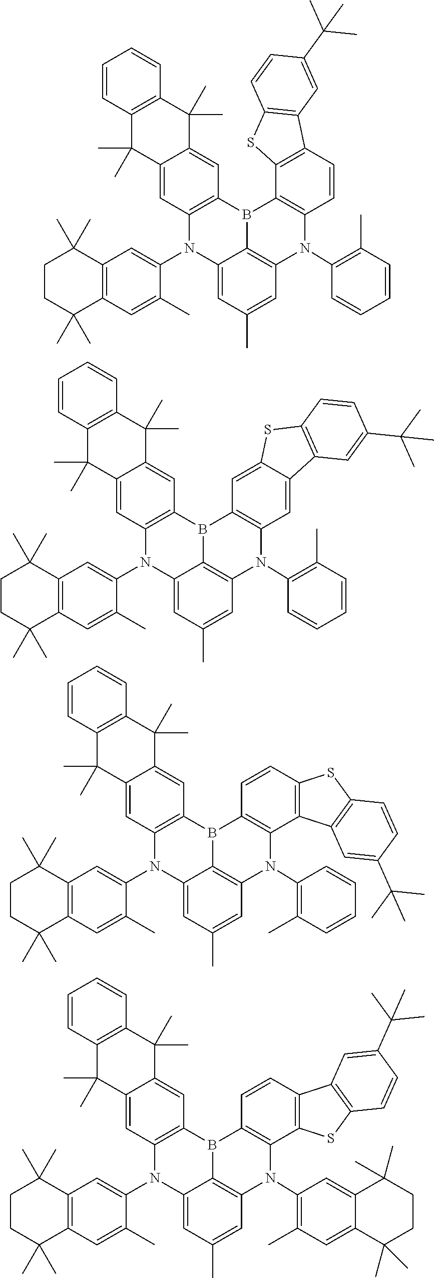

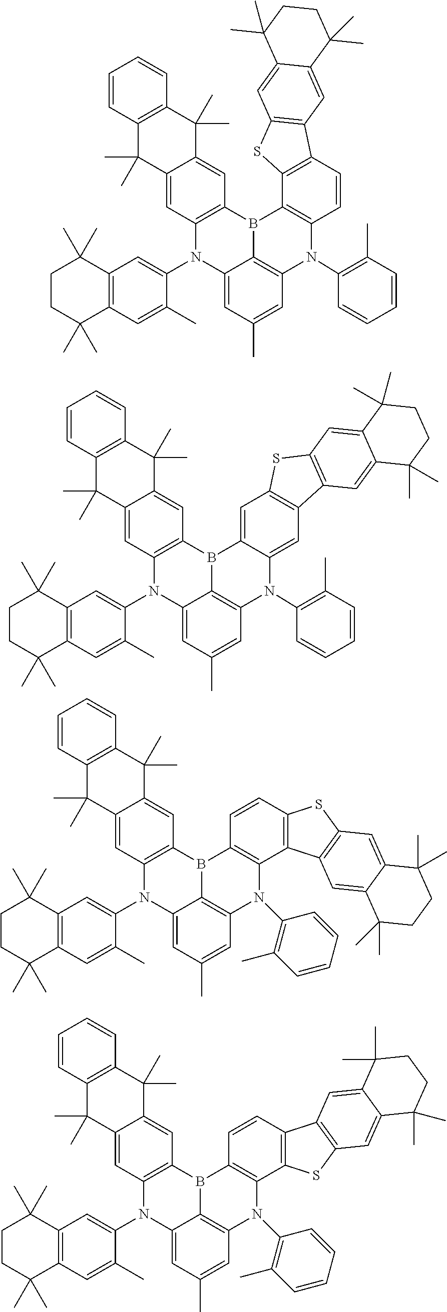

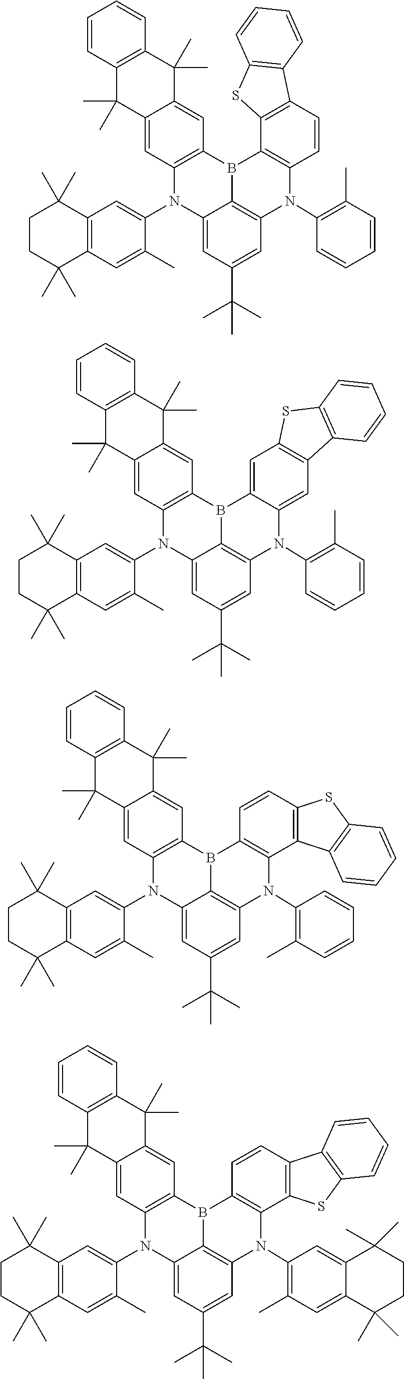 [SMILES: Cc1cc2c(cc1N1c3cc4c(cc3B3c5c1cc(C(C)(C)C)cc5N(c1ccccc1C)c1ccc5c(sc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)sc1ccccc13 ; Cc1cc2c(cc1N1c3cc4c(cc3B3c5ccc6sc7ccccc7c6c5N(c5ccccc5C)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(C(C)(C)C)cc1c53)C(C)(C)c1ccccc1C4(C)C)C(C)(C)CCC2(C)C]

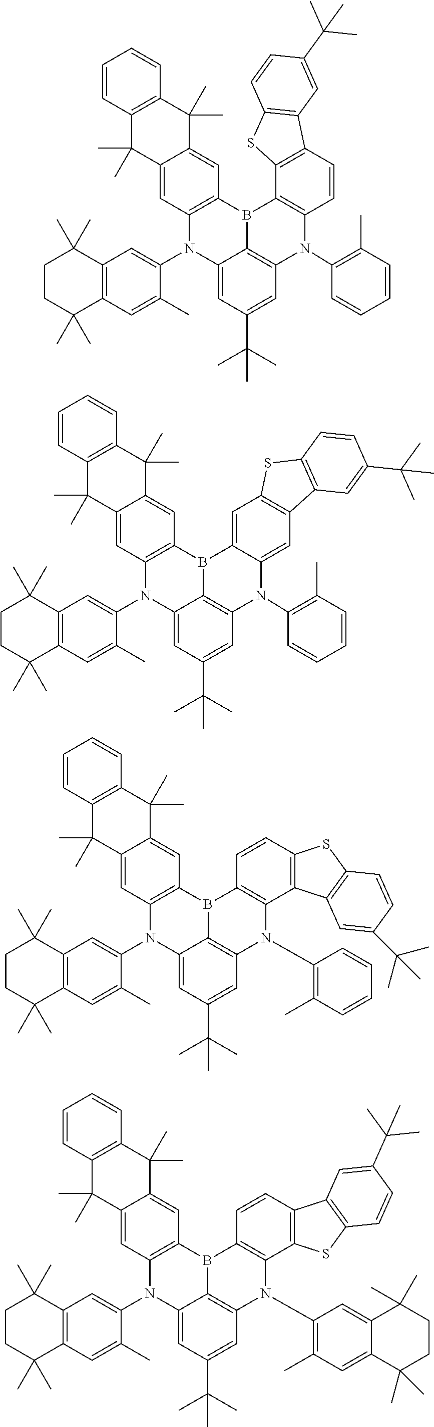

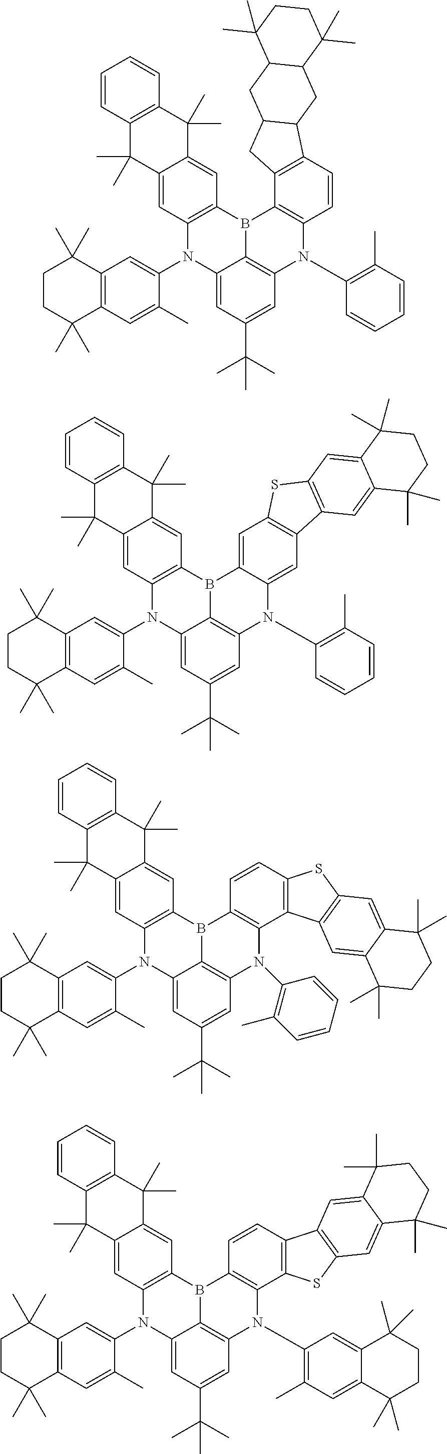

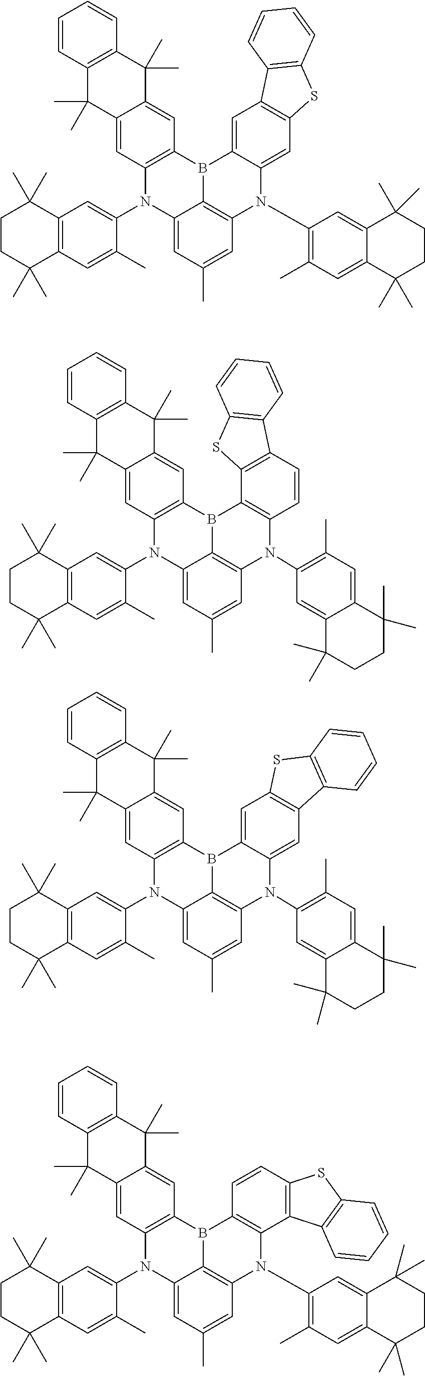

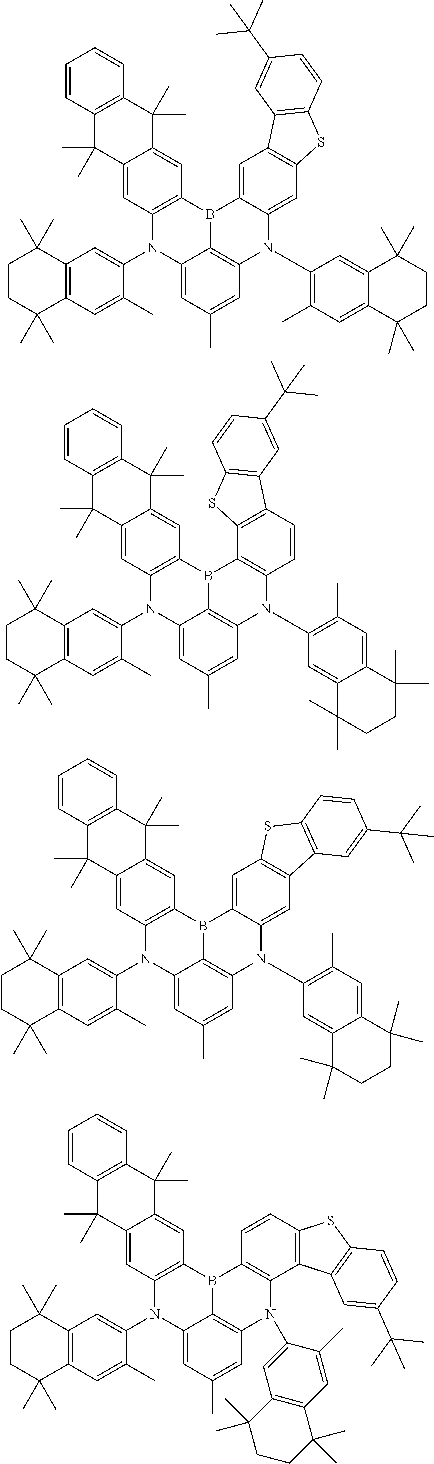

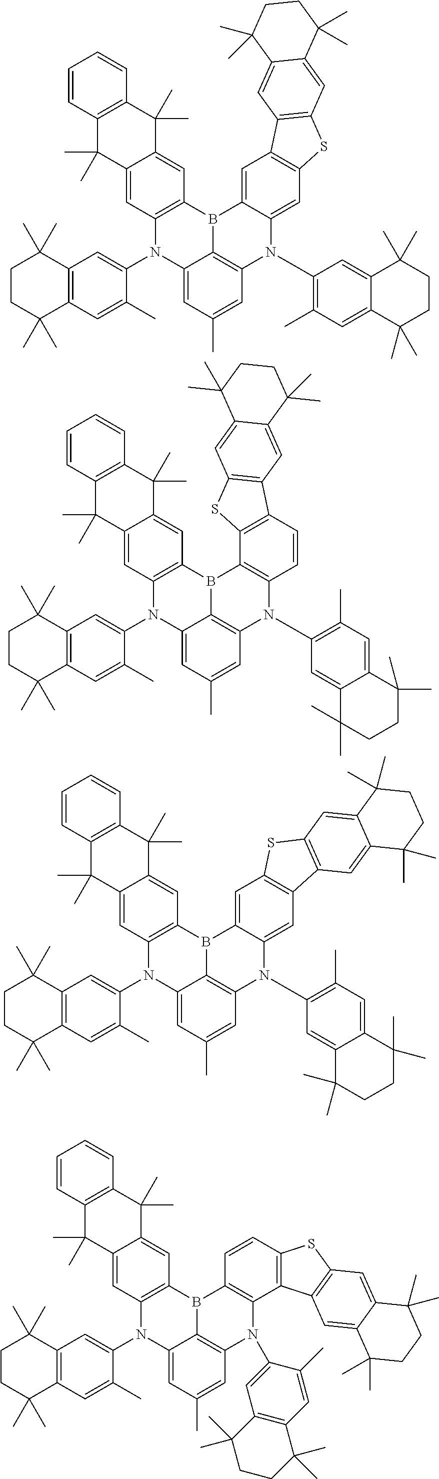

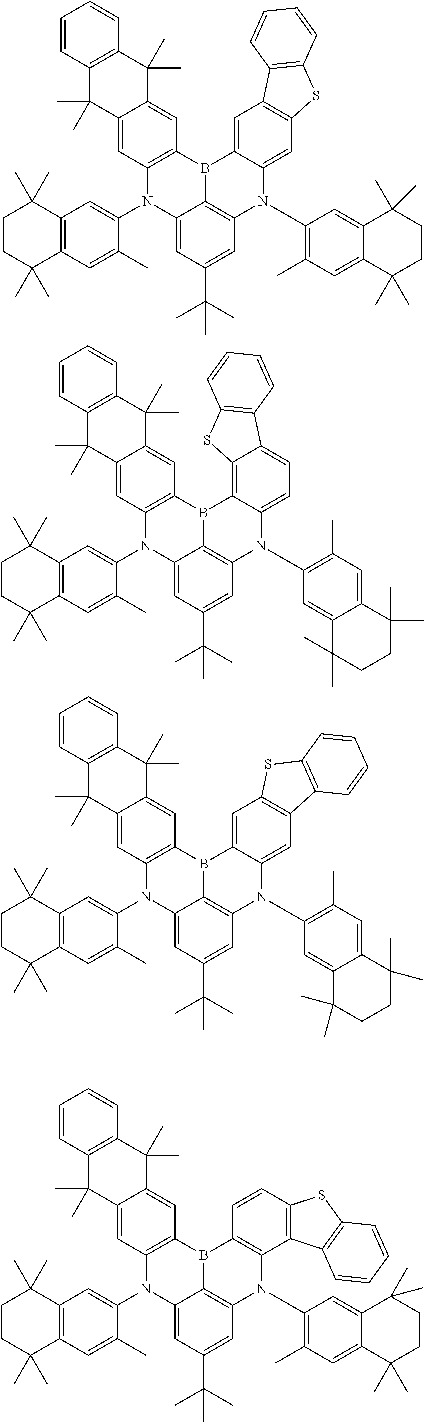

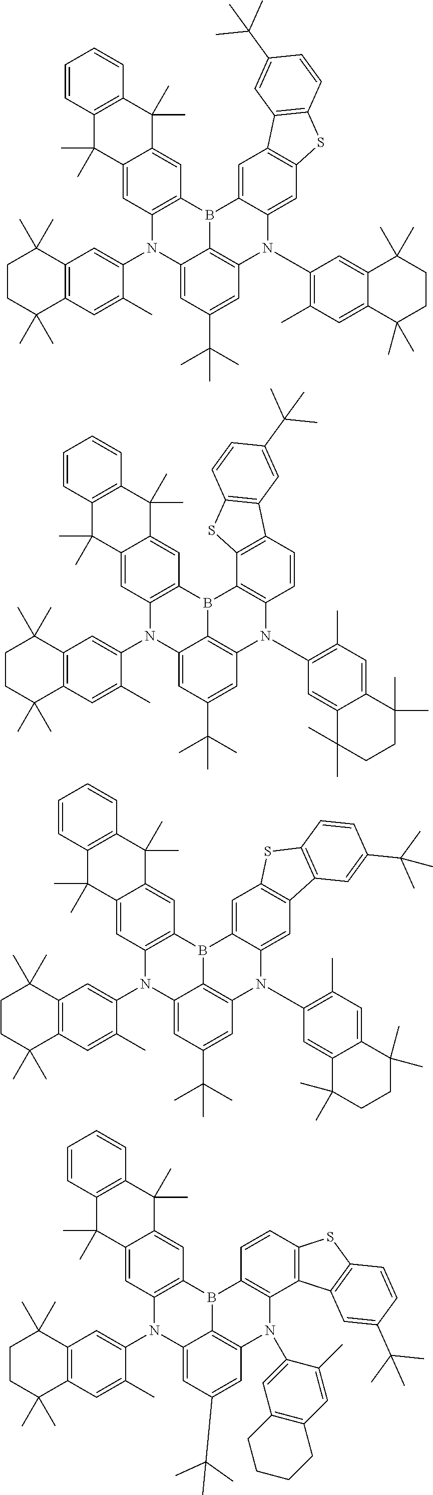

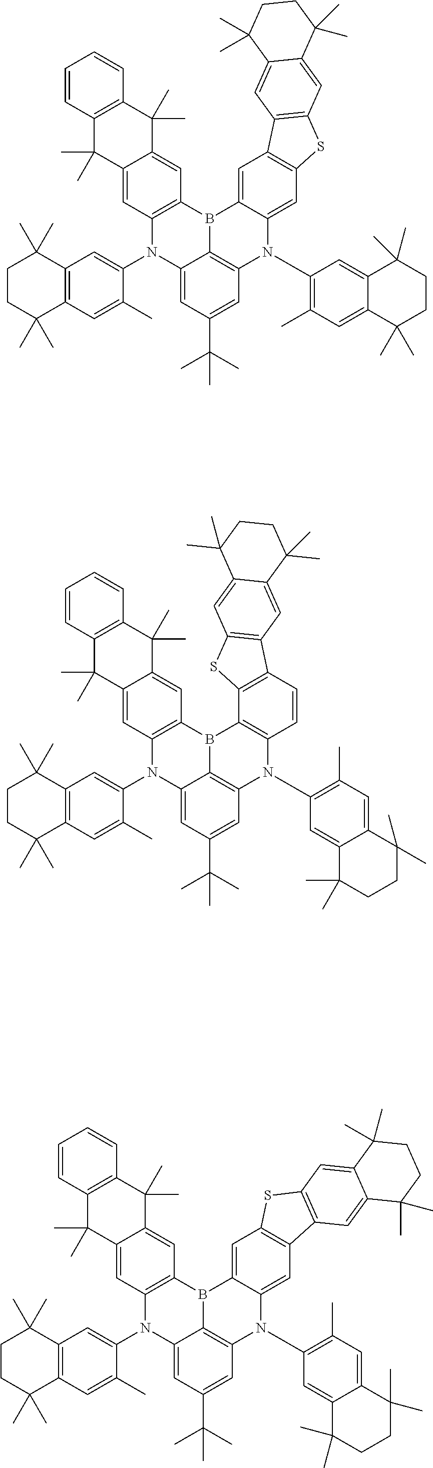 [SMILES: Cc1cc2c(cc1N1c3cc4c(cc3B3c5cc6c(cc5N(c5cc7c(cc5C)C(C)(C)CCC7(C)C)c5cc(C(C)(C)C)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5cc6c(cc5C)C(C)(C)CCC6(C)C)c5cc(C(C)(C)C)cc1c53)C(C)(C)CCC8(C)C)C(C)(C)c1ccccc1C4(C)C)C(C)(C)CCC2(C)C]

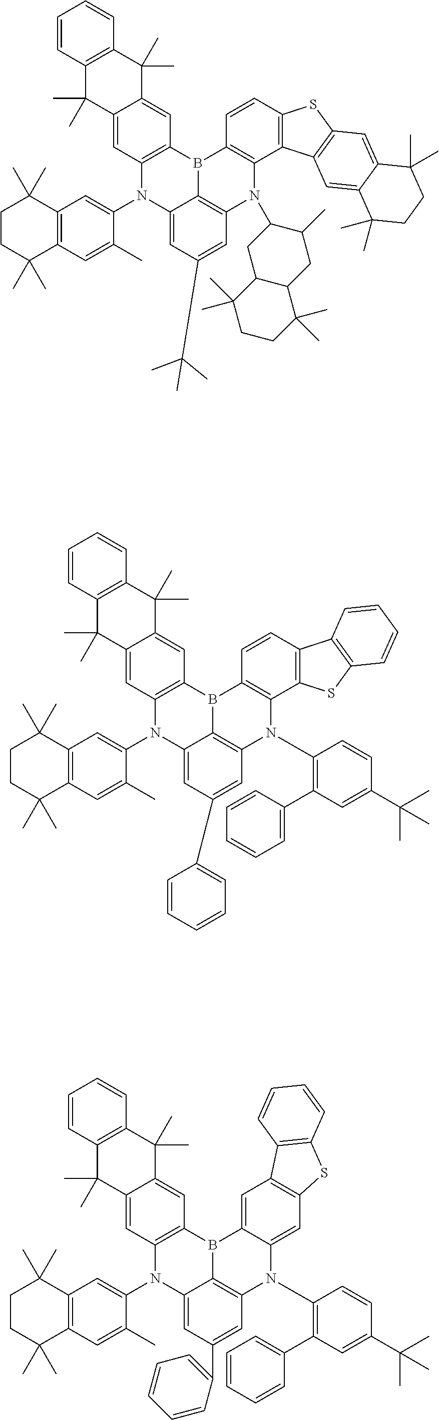 [SMILES: Cc1cc2c(cc1N1c3cc4c(cc3B3c5ccc6sc7cc8c(cc7c6c5N(C5CC6C(CC5C)C(C)(C)CCC6(C)C)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)sc1ccccc16)C(C)(C)c1ccccc1C4(C)C)C(C)(C)CCC2(C)C]

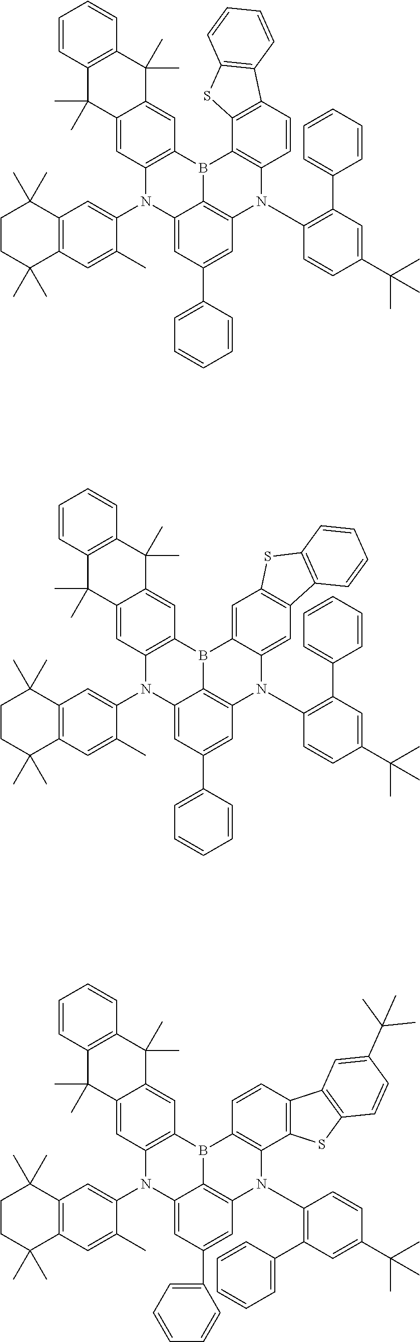 [SMILES: Cc1cc2c(cc1N1c3cc4c(cc3B3c5c1cc(-c1ccccc1)cc5N(c1ccc(C(C)(C)C)cc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C]

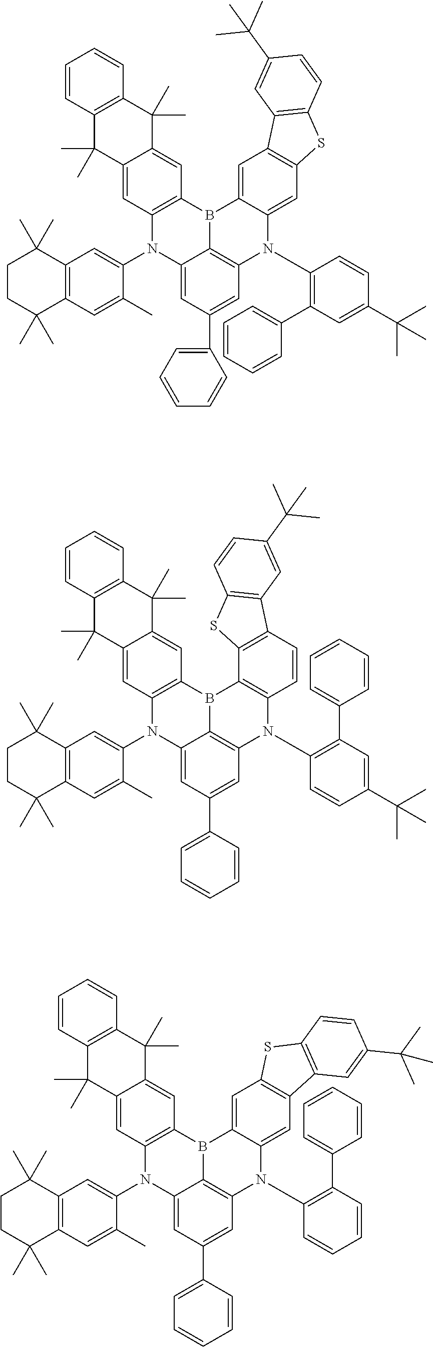 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6sc7ccc(C(C)(C)C)cc7c6cc5N(c5ccccc5-c5ccccc5)c5cc(-c6ccccc6)cc1c53)C(C)(C)c1ccccc1C4(C)C)C(C)(C)CCC2(C)C]

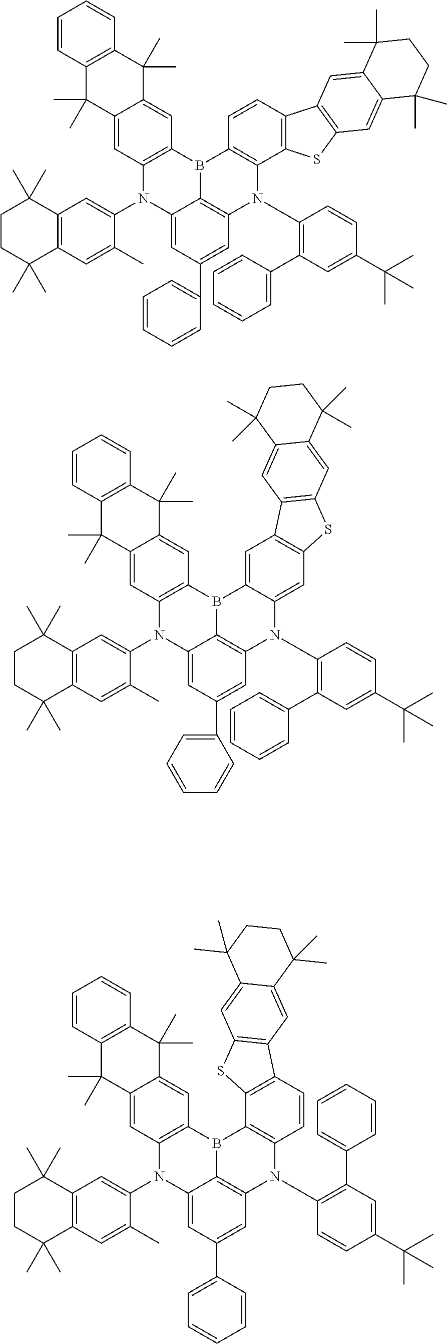 [SMILES: Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(sc6cc7c(cc65)C(C)(C)CCC7(C)C)c13)C(C)(C)c1ccccc1C4(C)C)C(C)(C)CCC2(C)C]

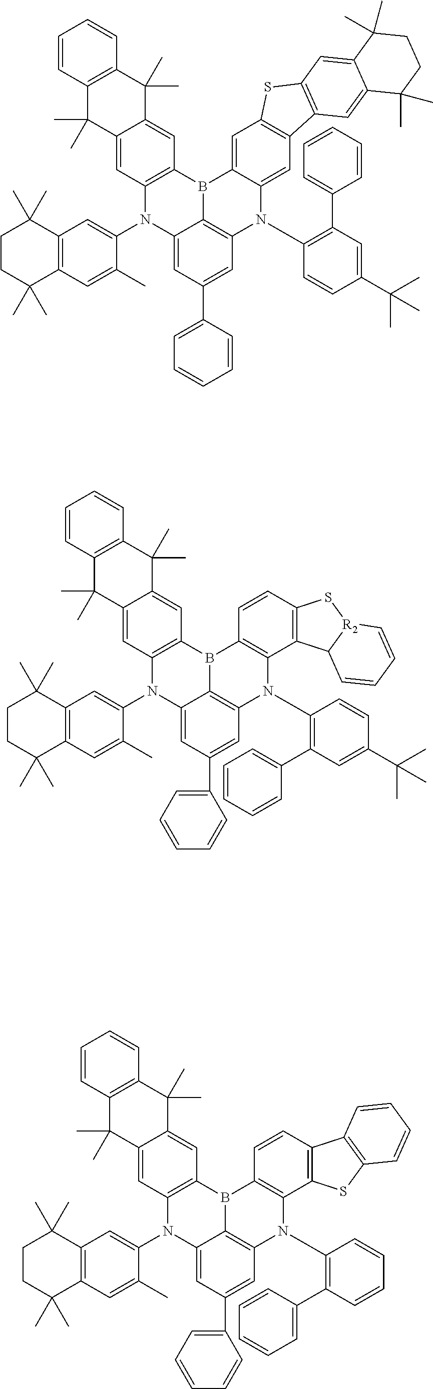

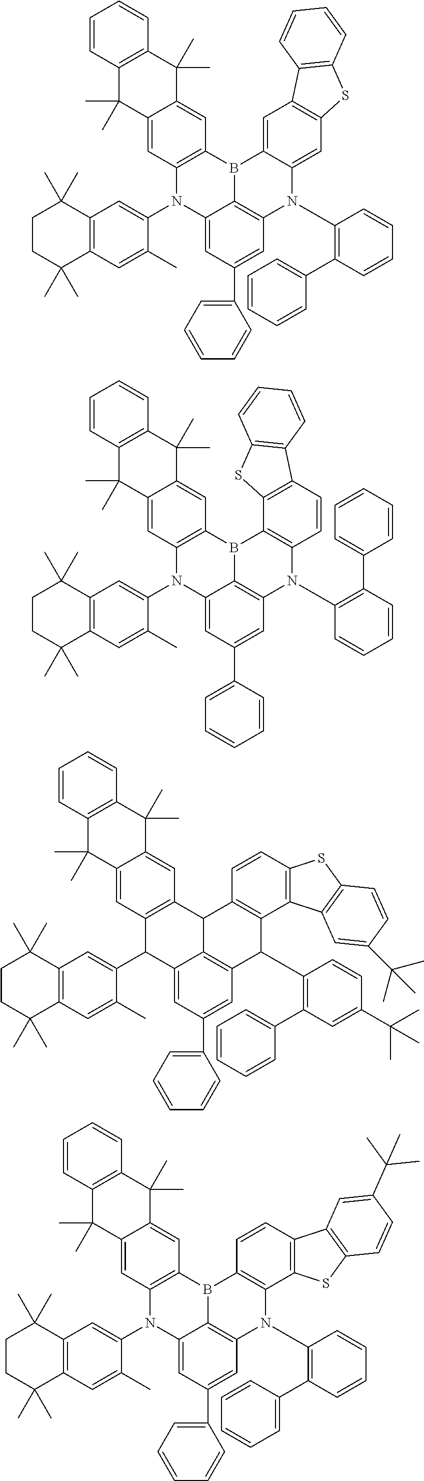

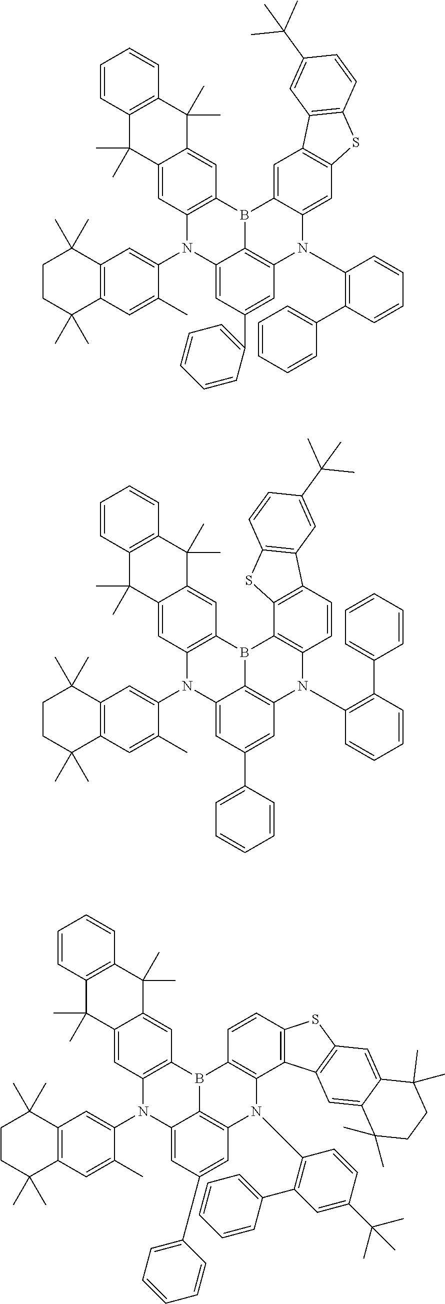 [SMILES: Cc1cc2c(cc1N1c3cc4c(cc3B3c5cc6c(cc5N(c5ccccc5-c5ccccc5)c5cc(-c7ccccc7)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(-c6ccccc6)cc1c53)C(C)(C)CCC8(C)C)C(C)(C)c1ccccc1C4(C)C)C(C)(C)CCC2(C)C]

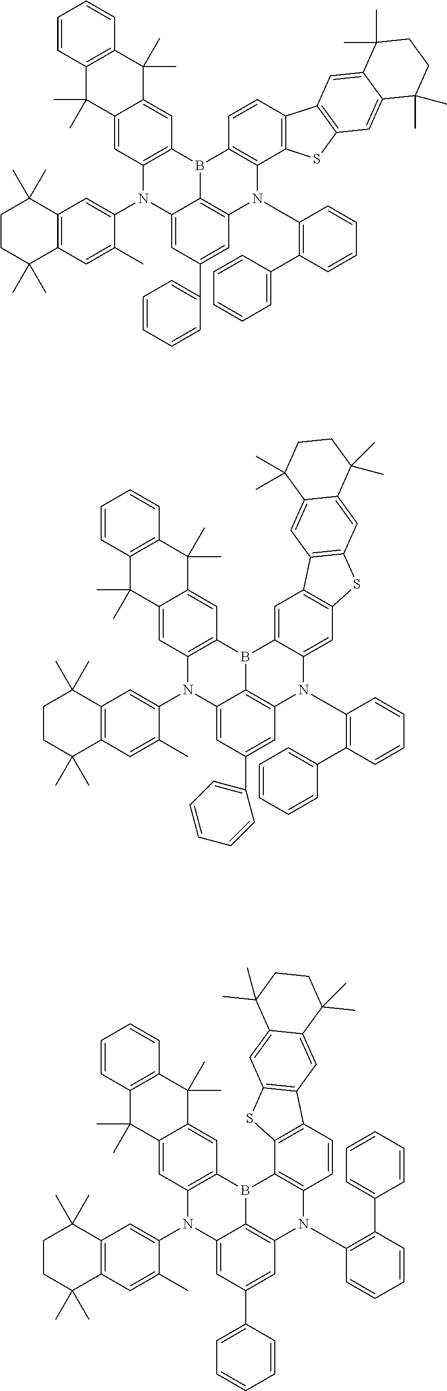 [SMILES: Cc1cc2c(cc1N1c3cc4c(cc3B3c5ccc6c(sc7cc8c(cc76)C(C)(C)CCC8(C)C)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(sc6cc7c(cc65)C(C)(C)CCC7(C)C)c13)C(C)(C)c1ccccc1C4(C)C)C(C)(C)CCC2(C)C]

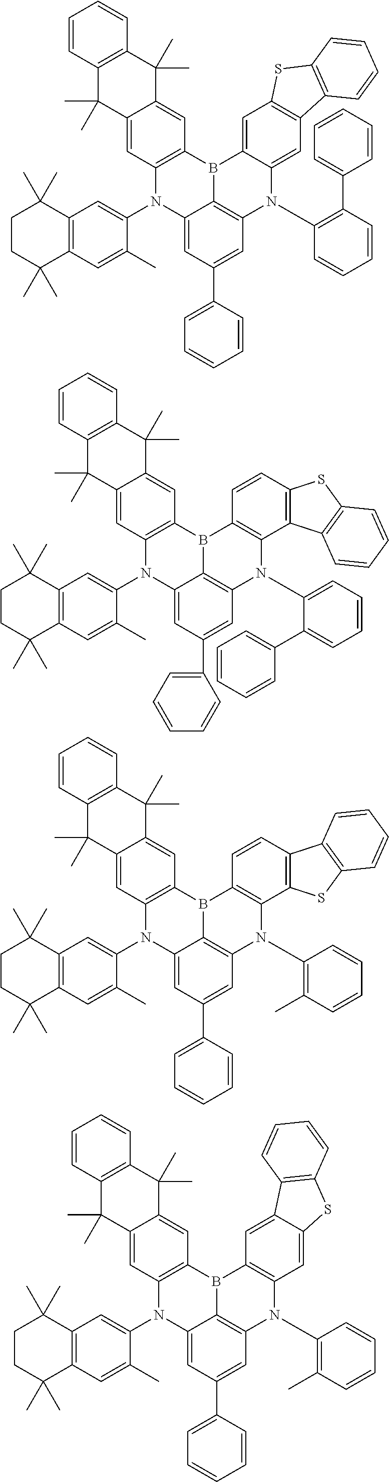

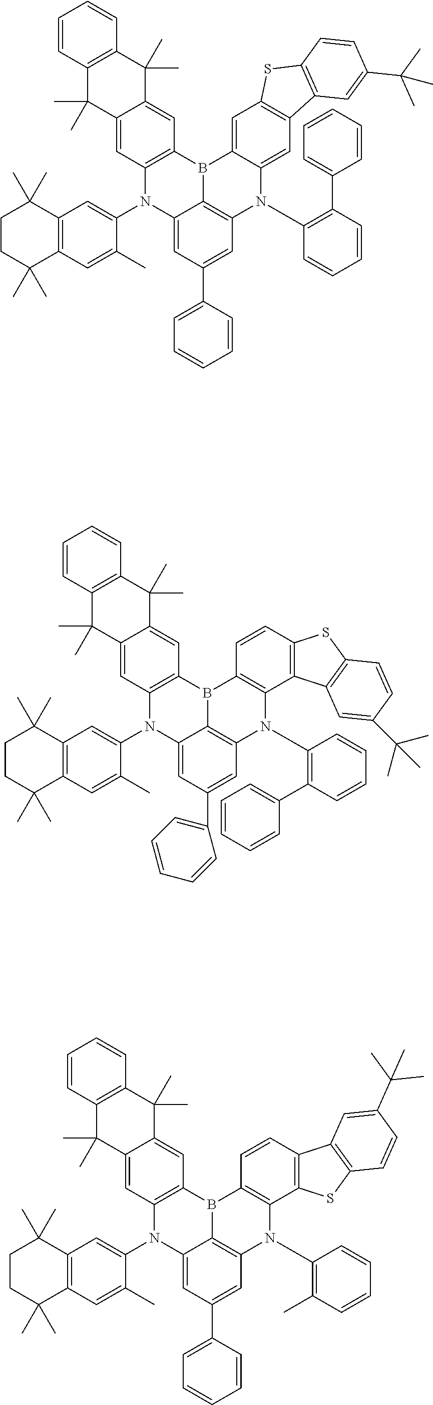 [SMILES: Cc1cc2c(cc1N1c3cc4c(cc3B3c5cc6sc7ccc(C(C)(C)C)cc7c6cc5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(-c6ccccc6)cc1c53)C(C)(C)c1ccccc1C4(C)C)C(C)(C)CCC2(C)C]

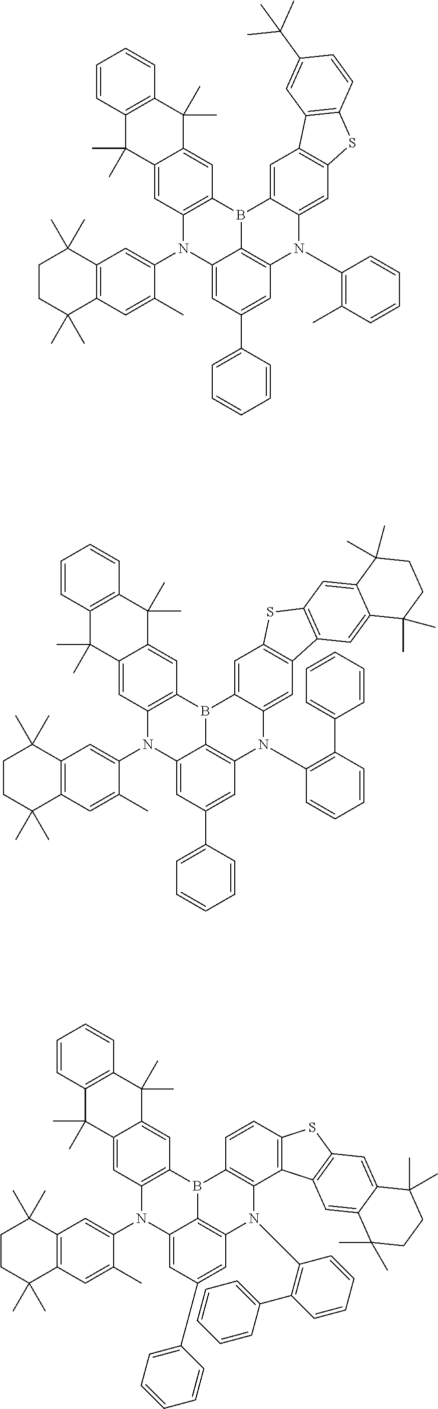 [SMILES: Cc1ccccc1N1c2cc3sc4ccc(C(C)(C)C)cc4c3cc2B2c3cc4c(cc3N(c3cc5c(cc3C)C(C)(C)CCC5(C)C)c3cc(-c5ccccc5)cc1c32)C(C)(C)c1ccccc1C4(C)C ; Cc1cc2c(cc1N1c3cc4c(cc3B3c5cc6sc7cc8c(cc7c6cc5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C]

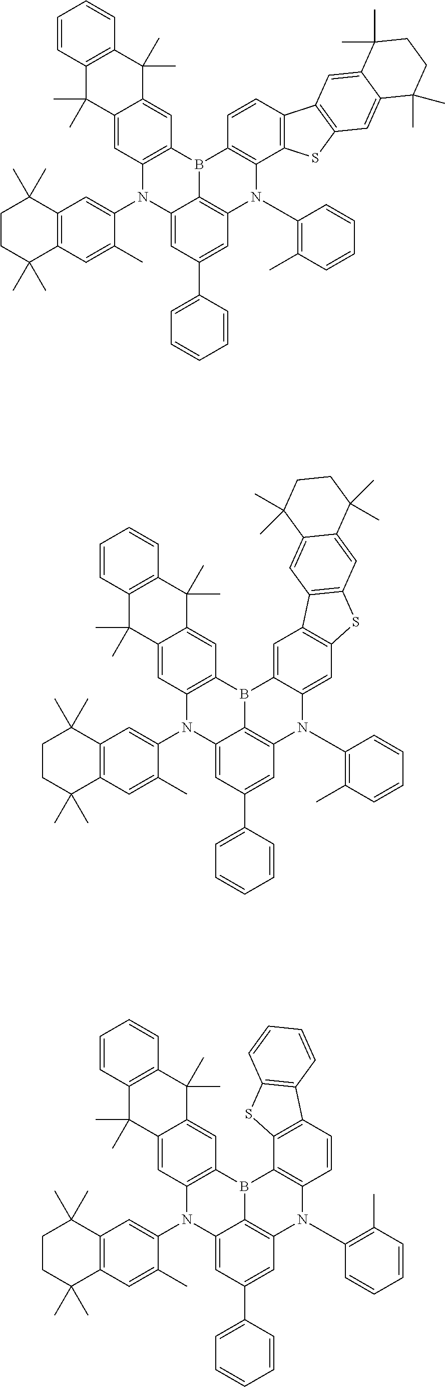 [SMILES: Cc1cc2c(cc1N1c3cc4c(cc3B3c5ccc6c(sc7cc8c(cc76)C(C)(C)CCC8(C)C)c5N(c5ccccc5C)c5cc(-c6ccccc6)cc1c53)C(C)(C)c1ccccc1C4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(-c6ccccc6)cc1c32)C(C)(C)c1ccccc1C4(C)C)C(C)(C)CCC5(C)C ; Cc1cc2c(cc1N1c3cc4c(cc3B3c5c1cc(-c1ccccc1)cc5N(c1ccccc1C)c1ccc5c(sc6ccccc65)c13)C(C)(C)c1ccccc1C4(C)C)C(C)(C)CCC2(C)C]

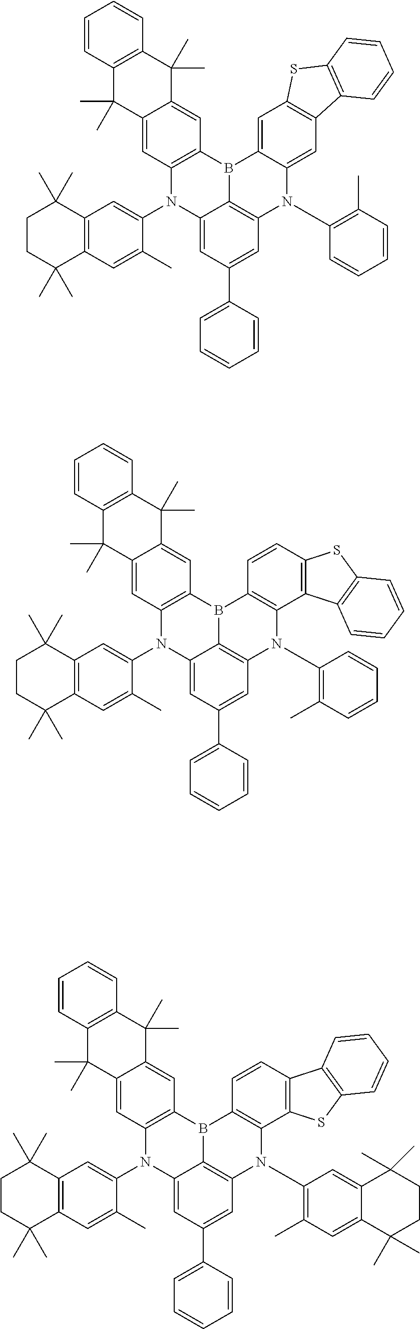 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)sc1ccccc13 ; Cc1cc2c(cc1N1c3cc4c(cc3B3c5ccc6sc7ccccc7c6c5N(c5ccccc5C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C]

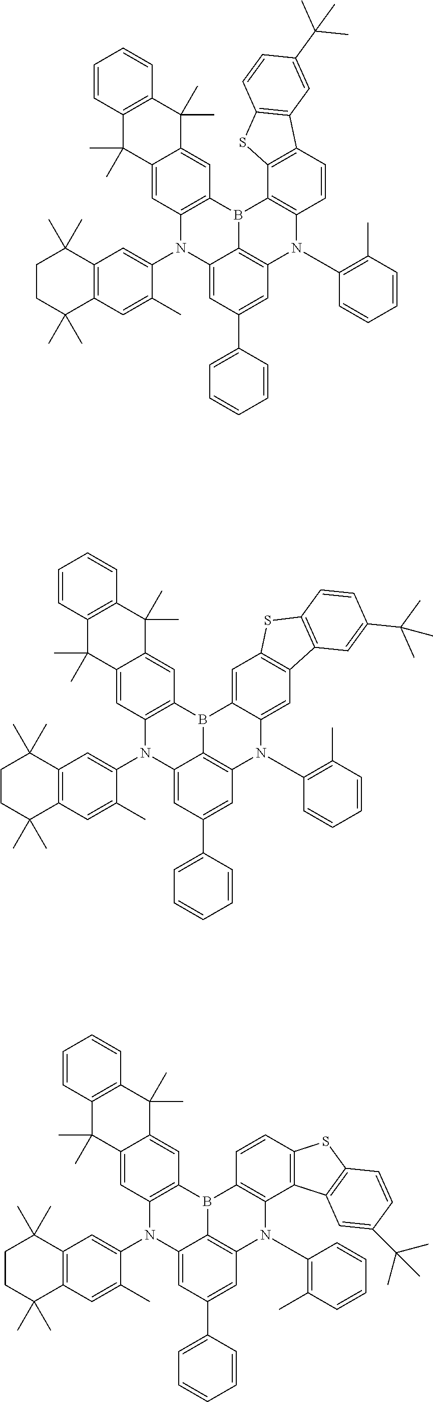 [SMILES: Cc1cc2c(cc1N1c3cc4c(cc3B3c5c1cc(-c1ccccc1)cc5N(c1ccccc1C)c1ccc5c(sc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)sc1ccc(C(C)(C)C)cc13 ; Cc1cc2c(cc1N1c3cc4c(cc3B3c5ccc6sc7ccc(C(C)(C)C)cc7c6c5N(c5ccccc5C)c5cc(-c6ccccc6)cc1c53)C(C)(C)c1ccccc1C4(C)C)C(C)(C)CCC2(C)C]

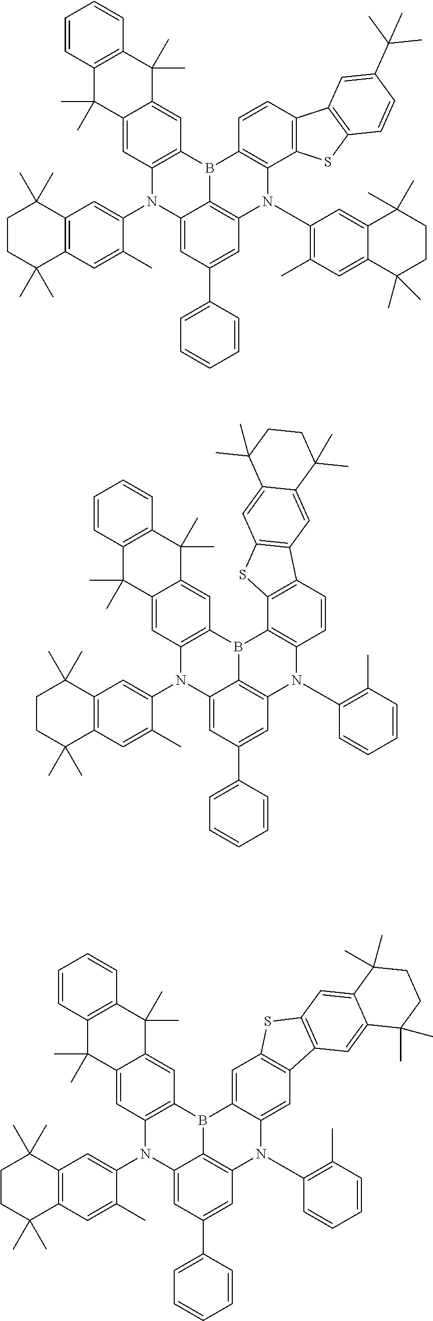 [SMILES: Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1C)c1ccc5c(sc6cc7c(cc65)C(C)(C)CCC7(C)C)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)sc1cc2c(cc13)C(C)(C)CCC2(C)C]

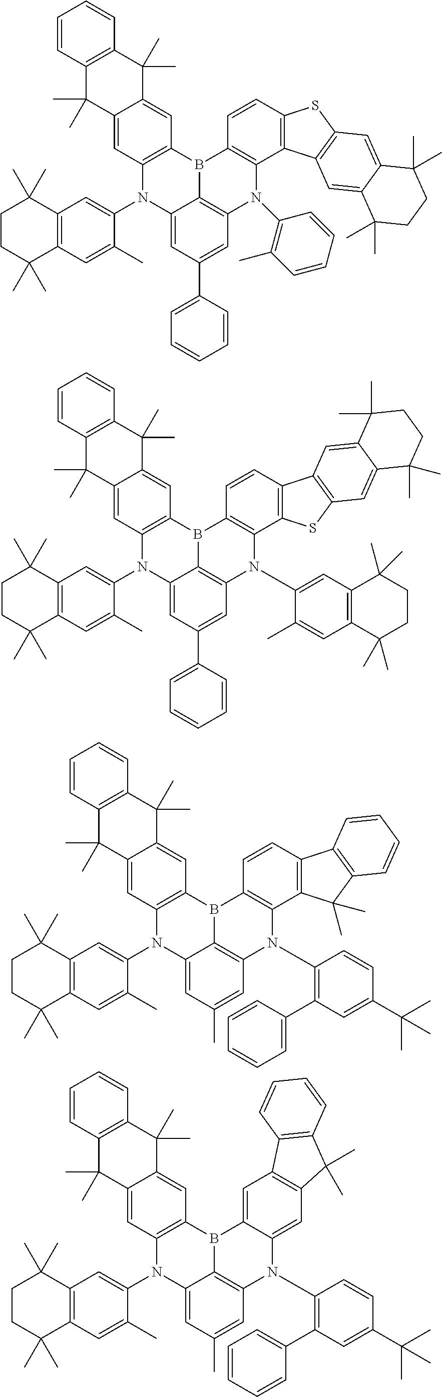

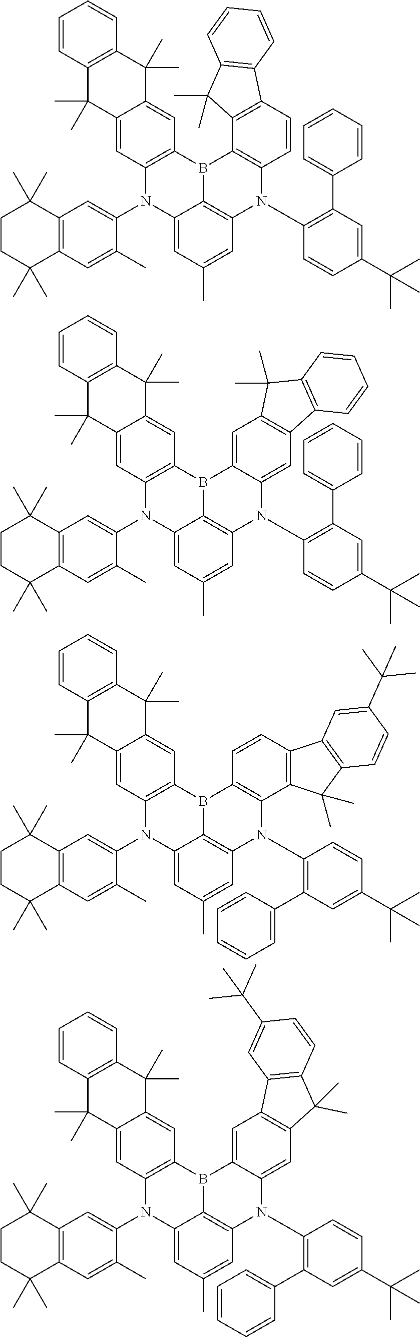

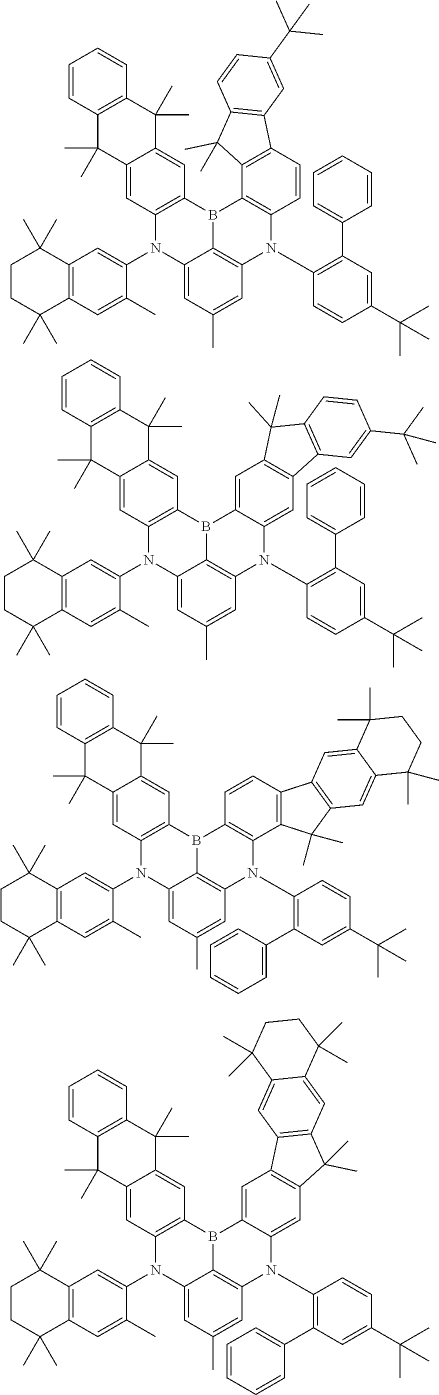

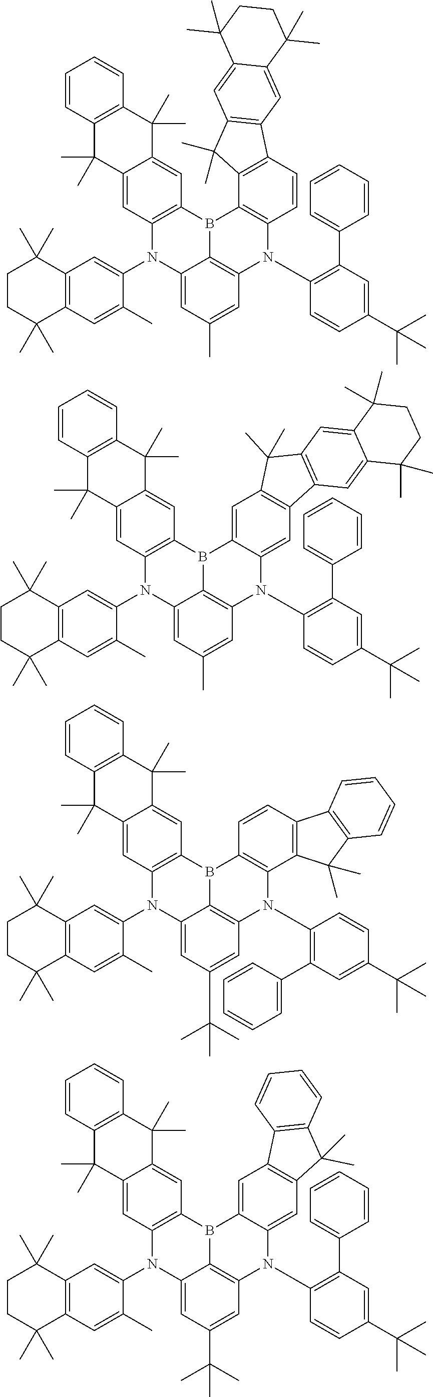

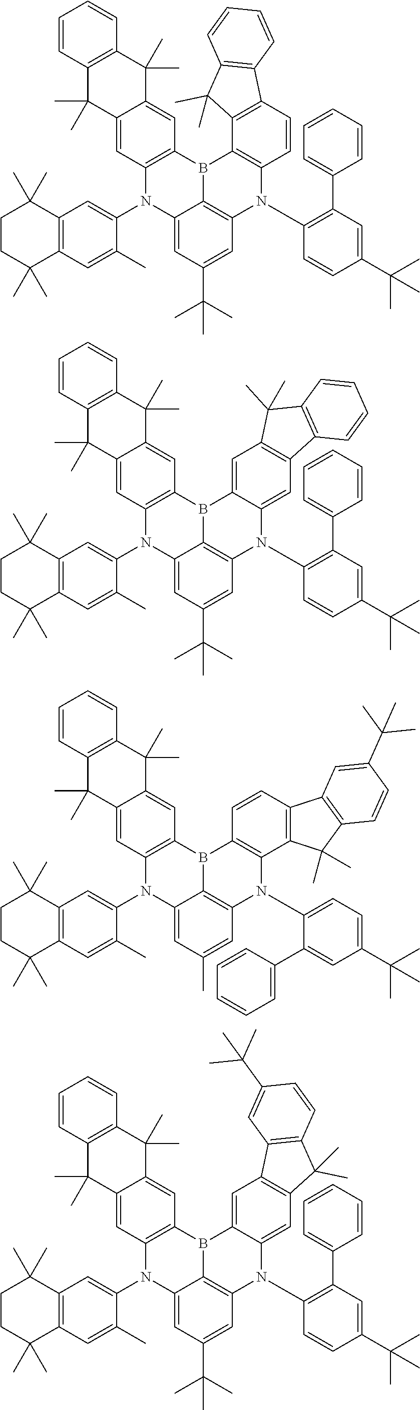

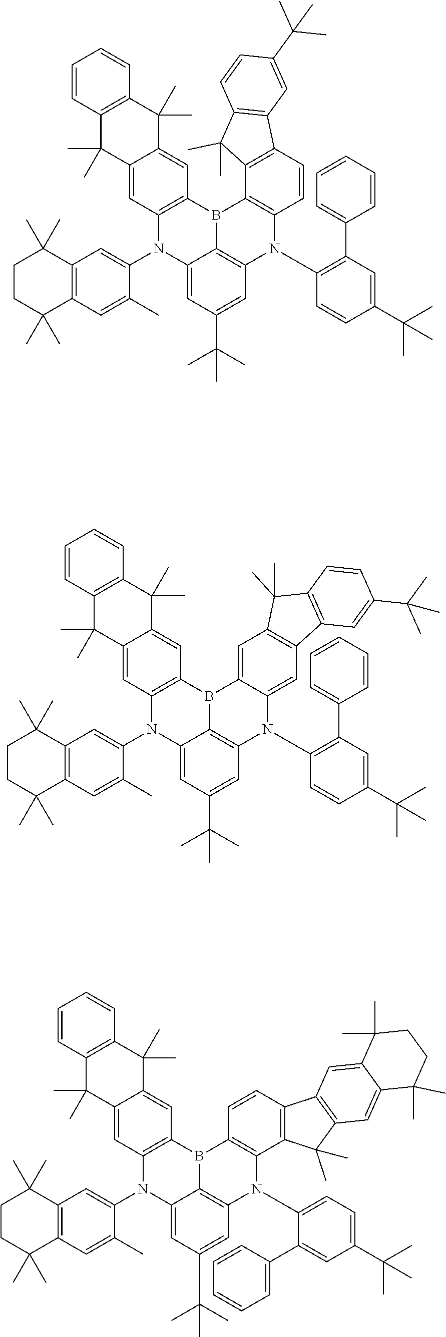 [SMILES: Cc1cc2c(cc1N1c3cc4c(cc3B3c5c1cc(C(C)(C)C)cc5N(c1ccc(C(C)(C)C)cc1-c1ccccc1)c1ccc5c(c13)C(C)(C)c1ccc(C(C)(C)C)cc1-5)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C]

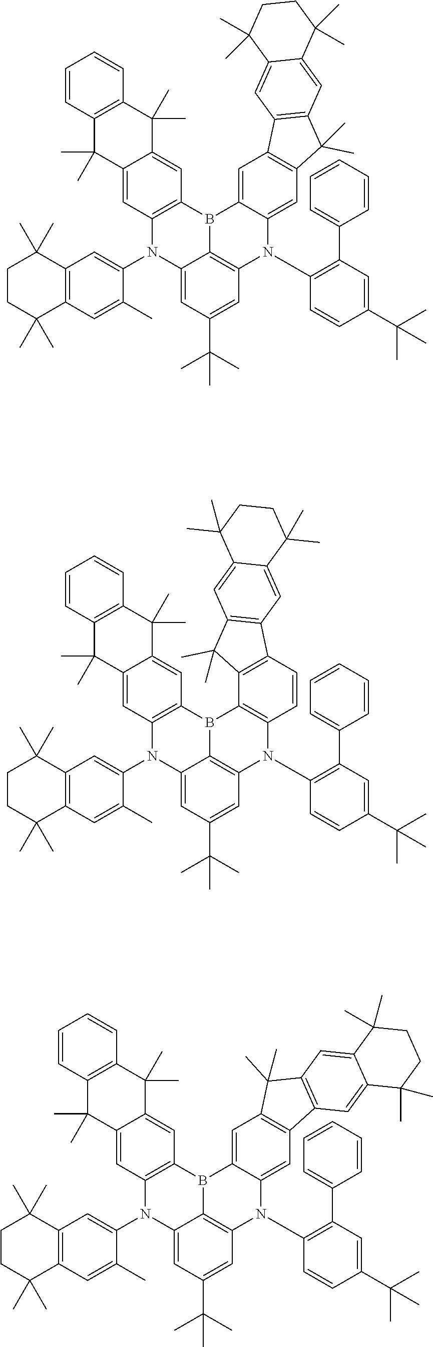 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(c13)C(C)(C)c1cc3c(cc1-5)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)-c1cc3c(cc1C6(C)C)C(C)(C)CCC3(C)C)C(C)(C)c1ccccc1C4(C)C)C(C)(C)CCC2(C)C]

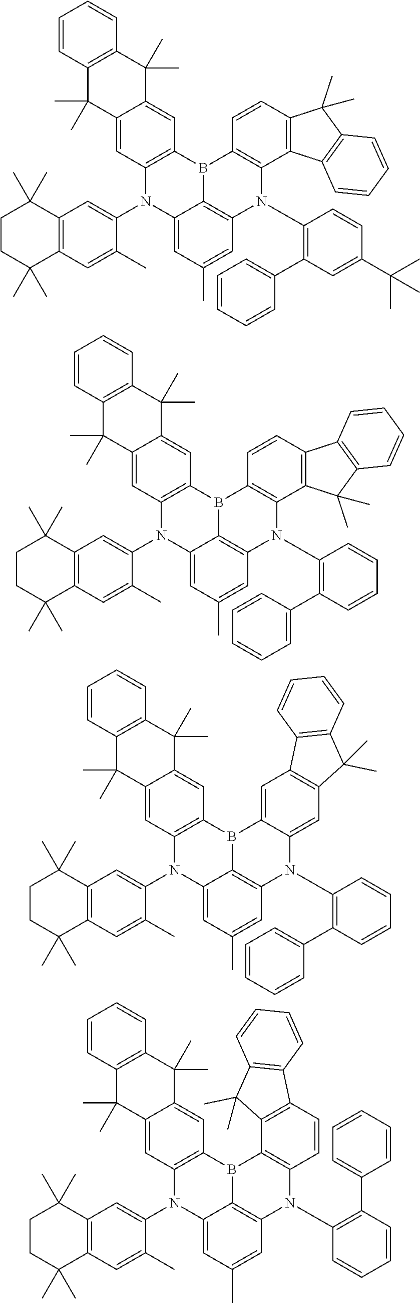

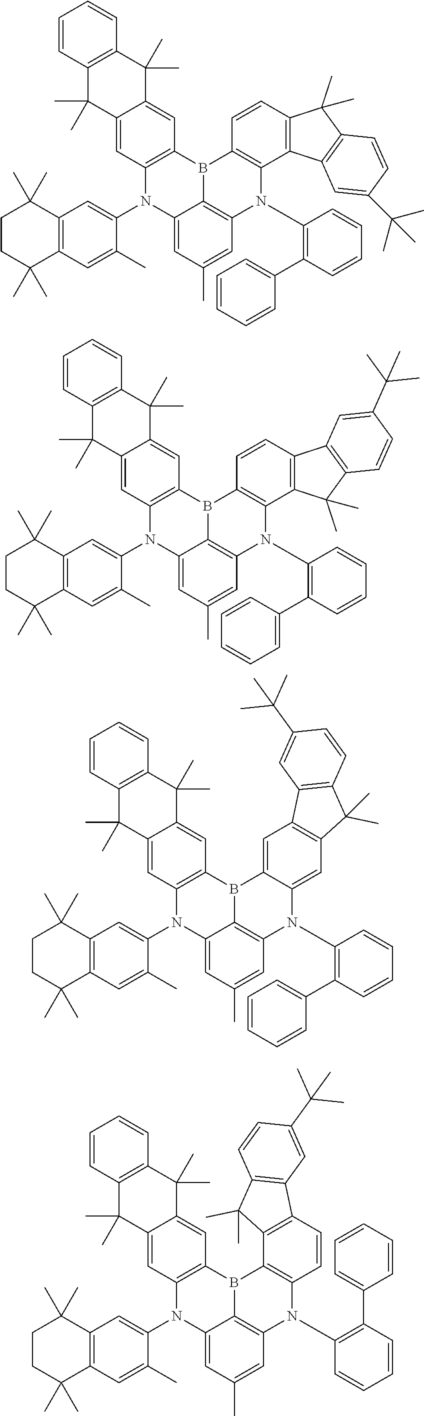

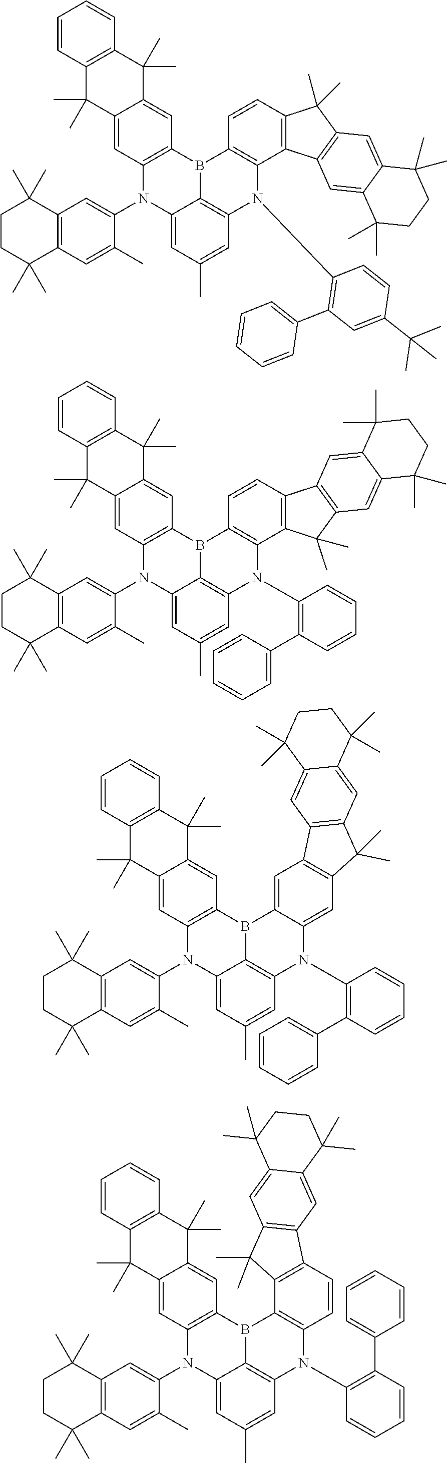

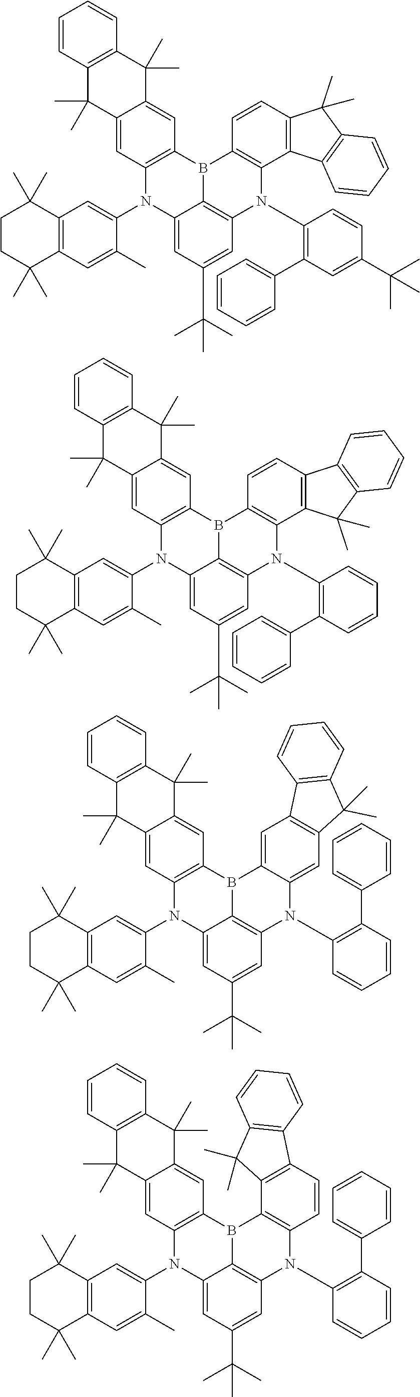

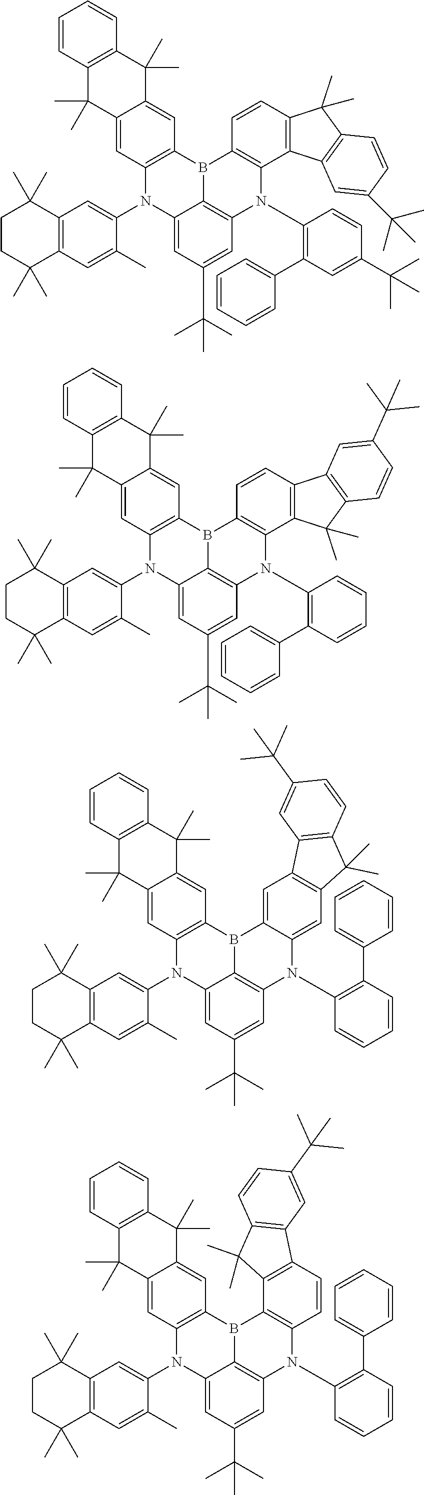

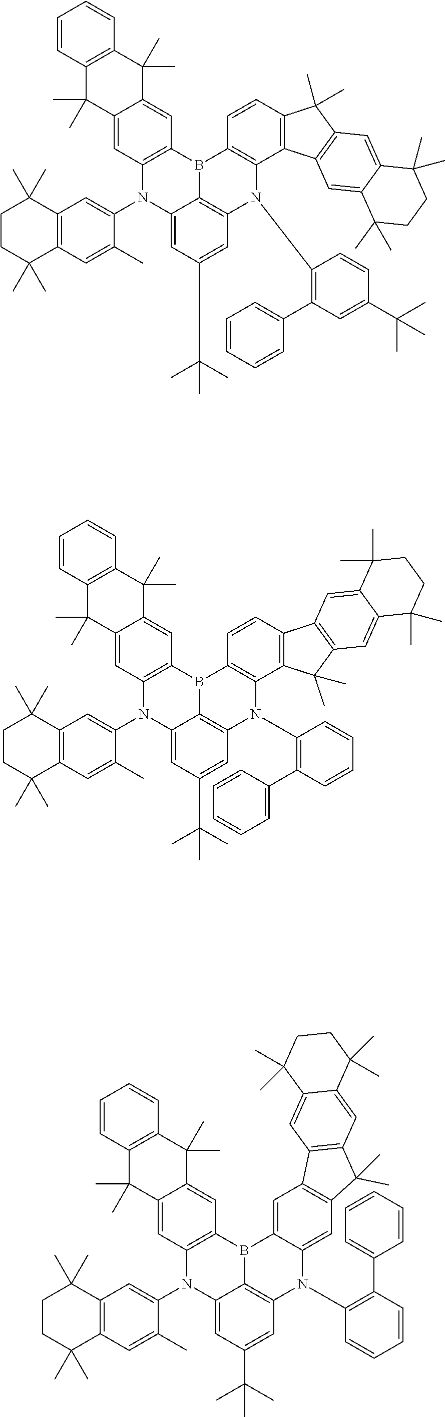 [SMILES: Cc1cc2c(cc1N1c3cc4c(cc3B3c5ccc6c(c5N(c5ccc(C(C)(C)C)cc5-c5ccccc5)c5cc(C(C)(C)C)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C]

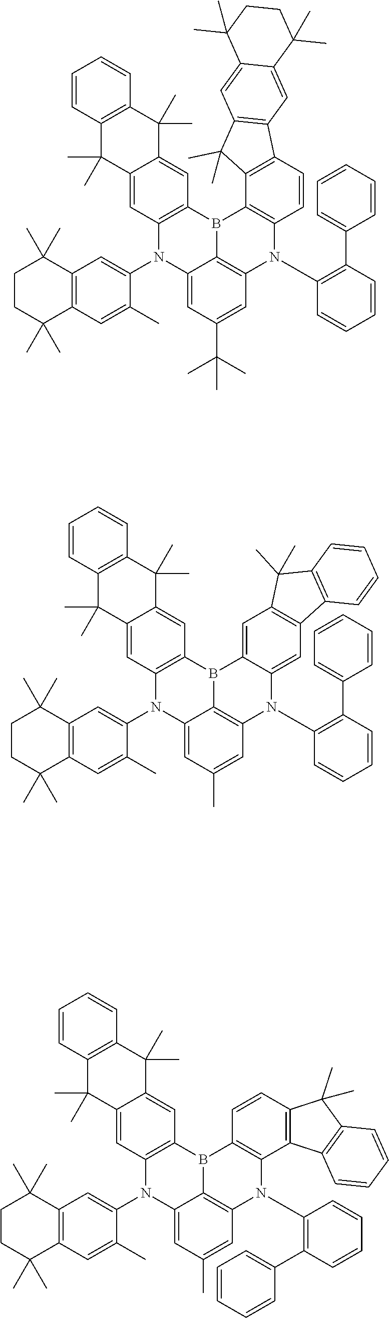 [SMILES: Cc1cc2c(cc1N1c3cc4c(cc3B3c5c1cc(C(C)(C)C)cc5N(c1ccccc1-c1ccccc1)c1ccc5c(c13)C(C)(C)c1cc3c(cc1-5)C(C)(C)CCC3(C)C)C(C)(C)c1ccccc1C4(C)C)C(C)(C)CCC2(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)C(C)(C)c1ccccc1-4 ; Cc1cc2c3c(c1)N(c1ccccc1-c1ccccc1)c1c(ccc4c1-c1ccccc1C4(C)C)B3c1cc3c(cc1N2c1cc2c(cc1C)C(C)(C)CCC2(C)C)C(C)(C)c1ccccc1C3(C)C]

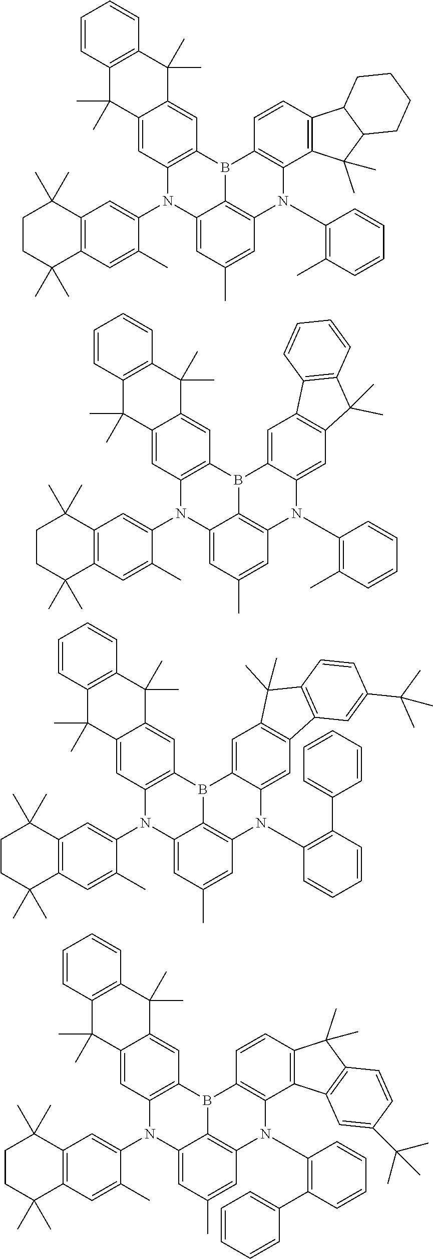

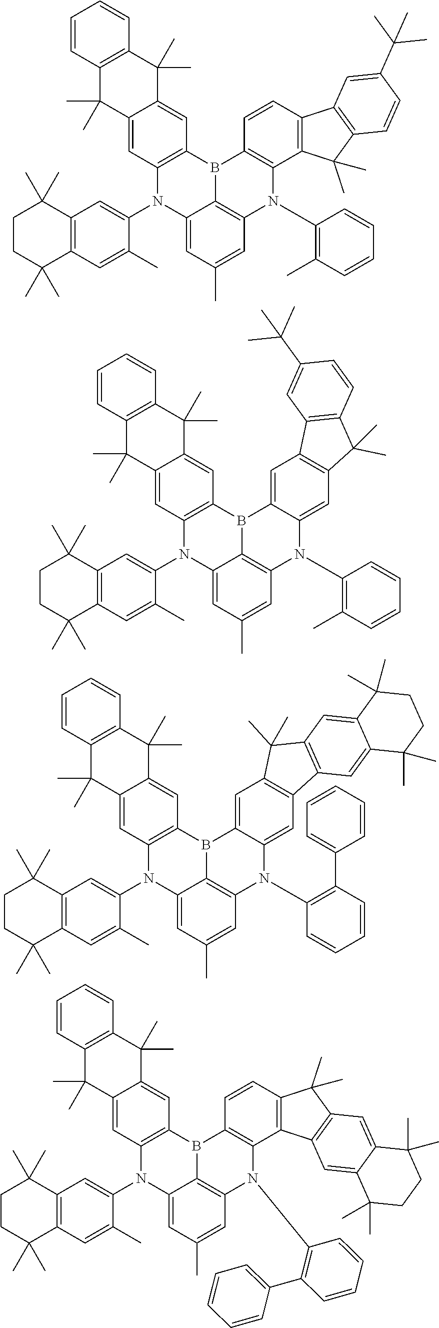

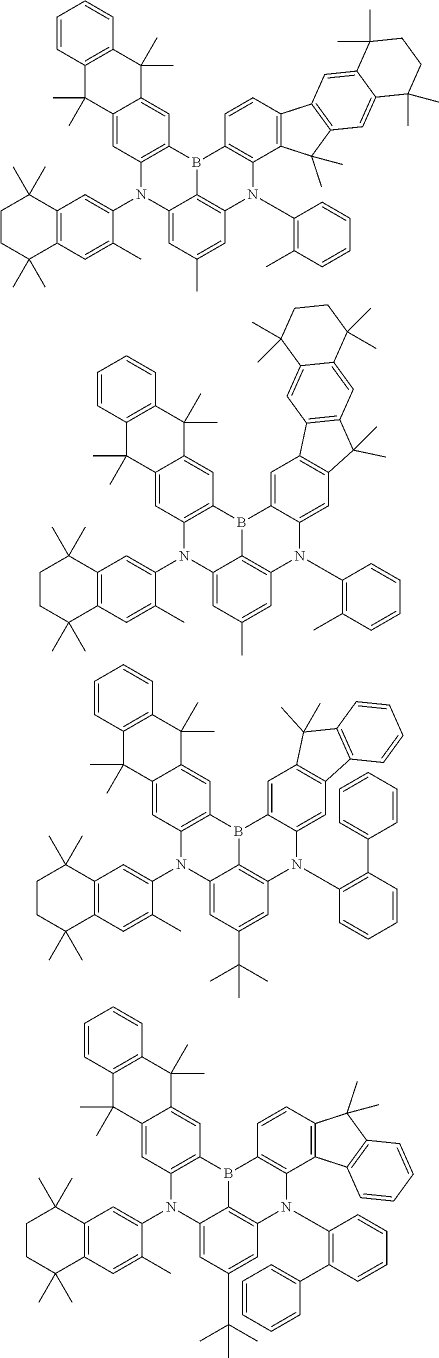

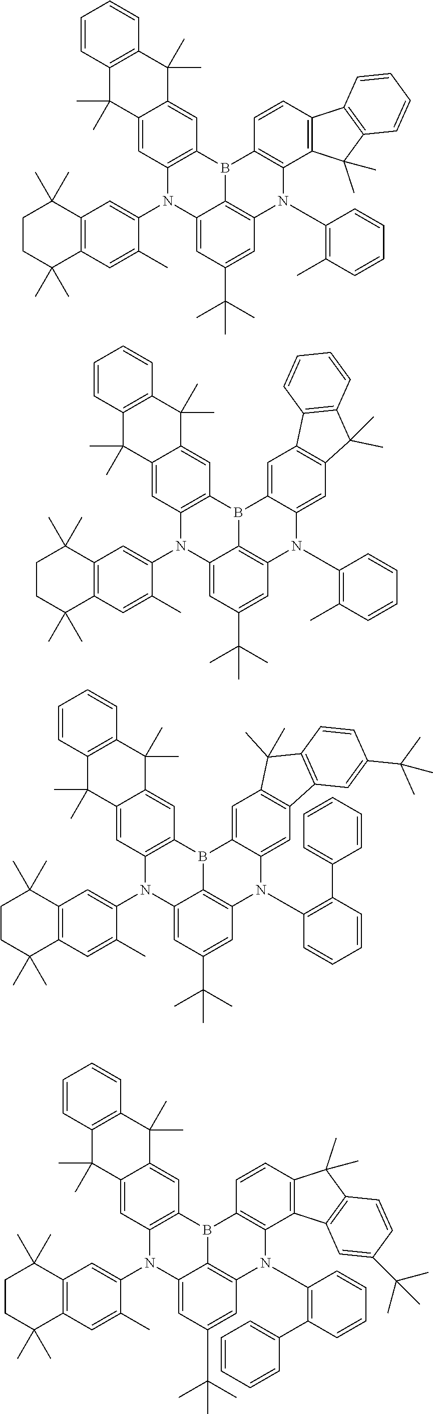

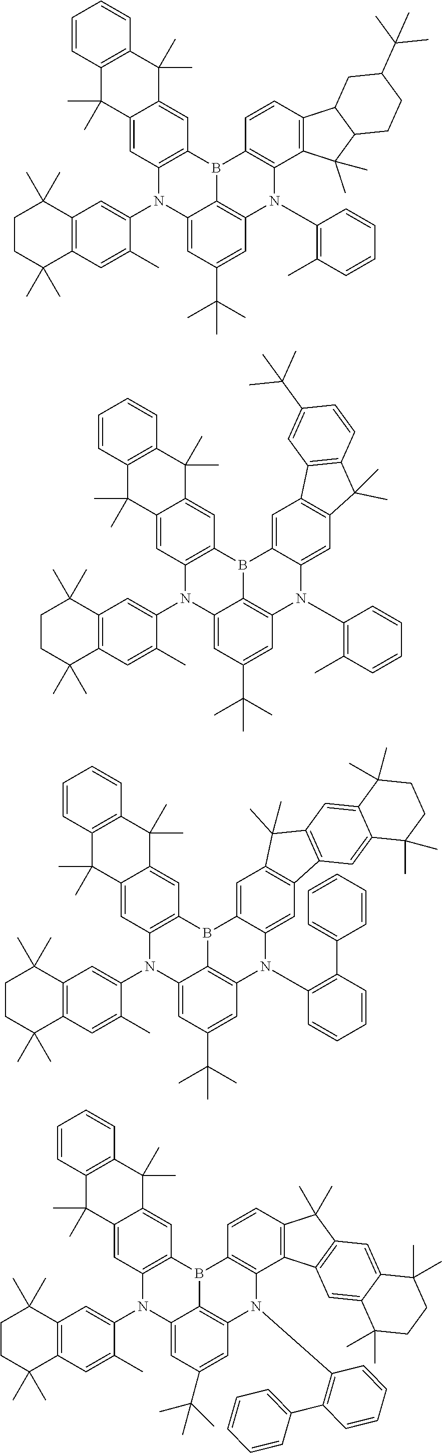

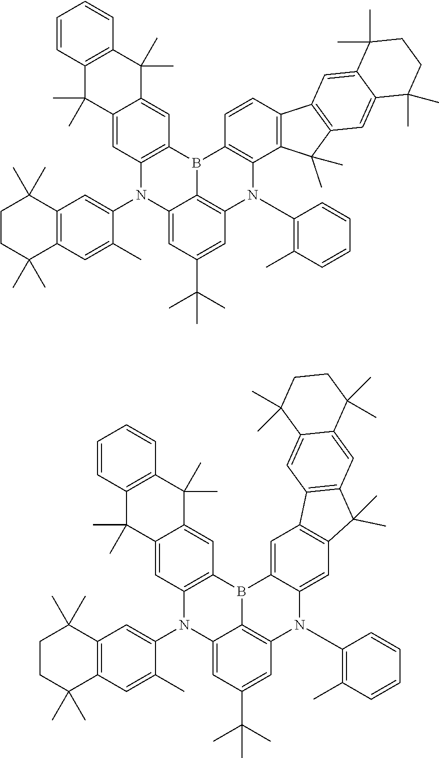 [SMILES: Cc1cc2c(cc1N1c3cc4c(cc3B3c5ccc6c(c5N(c5ccccc5C)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)-c1cc2c(cc1C3(C)C)C(C)(C)CCC2(C)C]

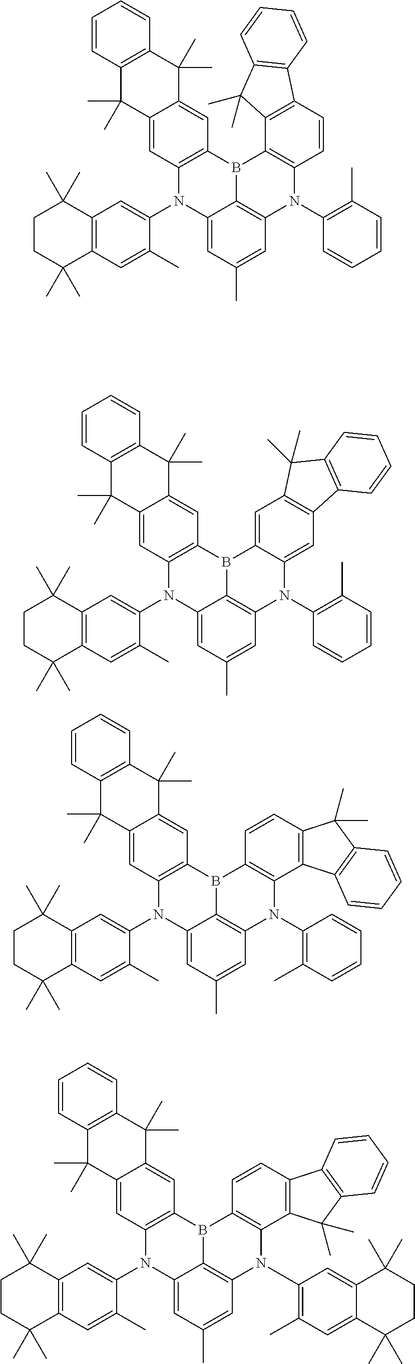

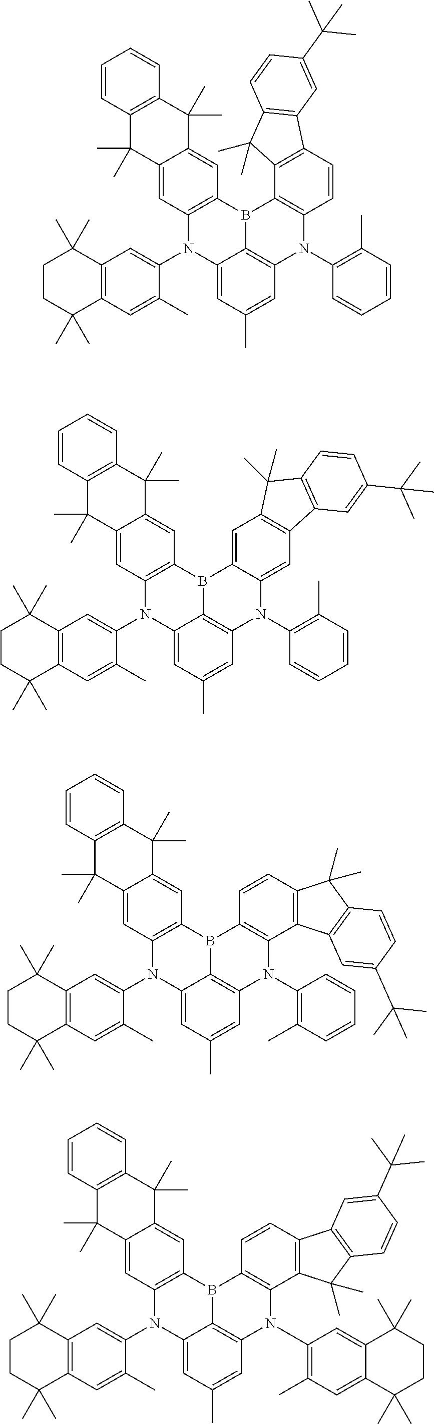

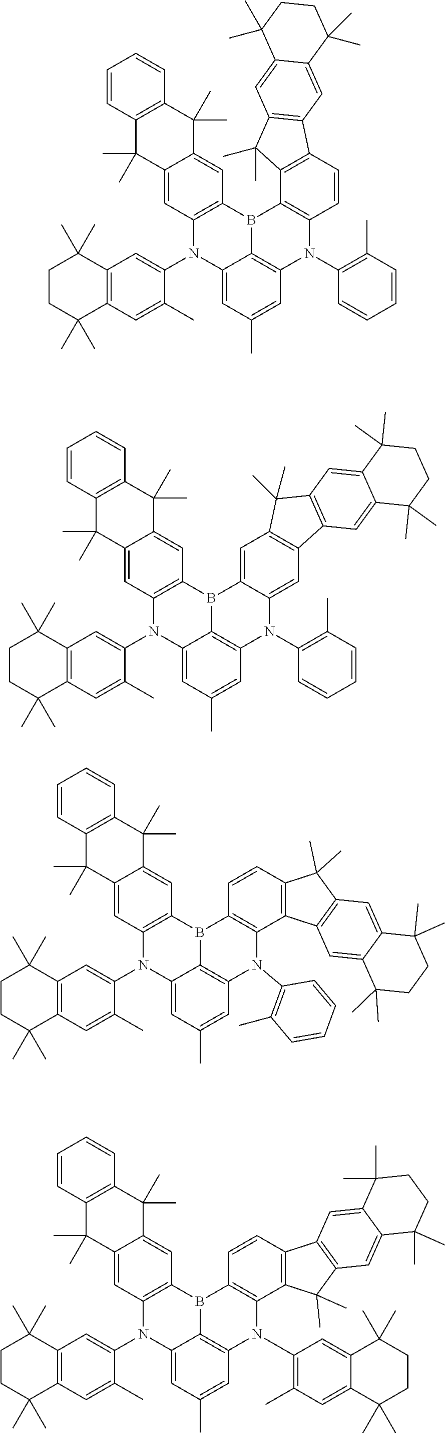

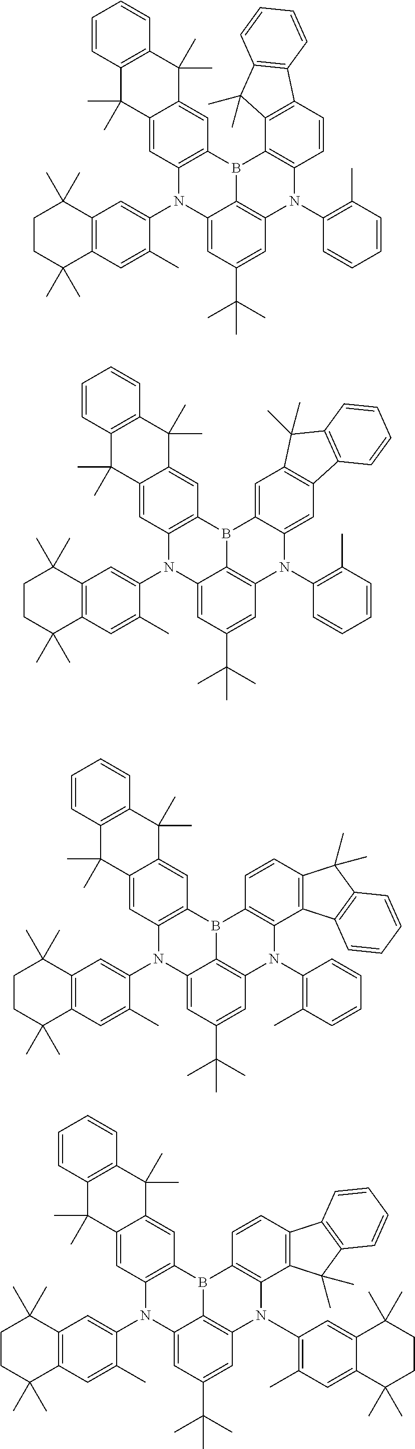

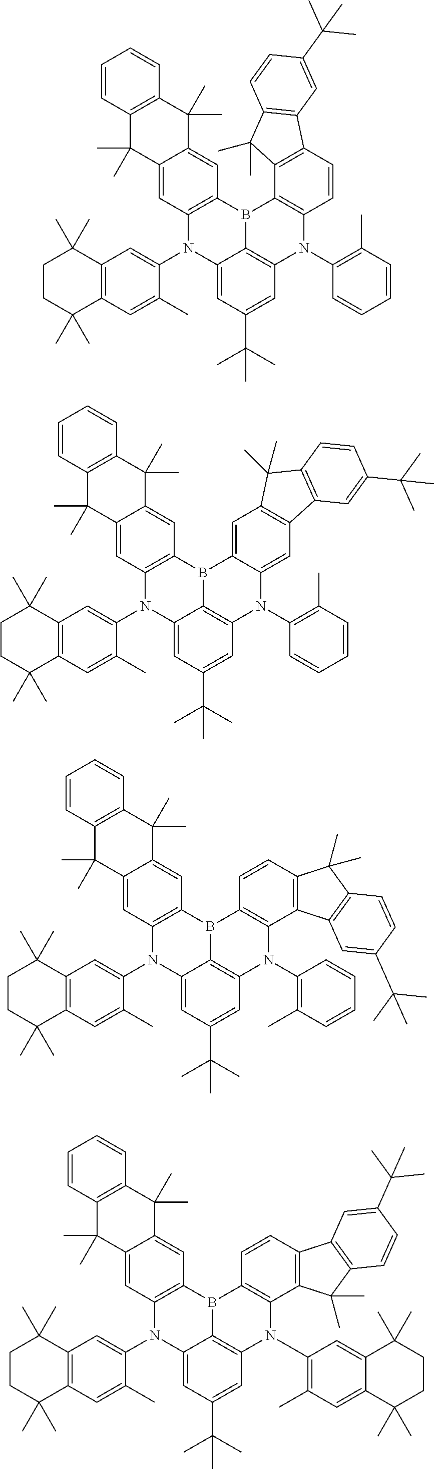

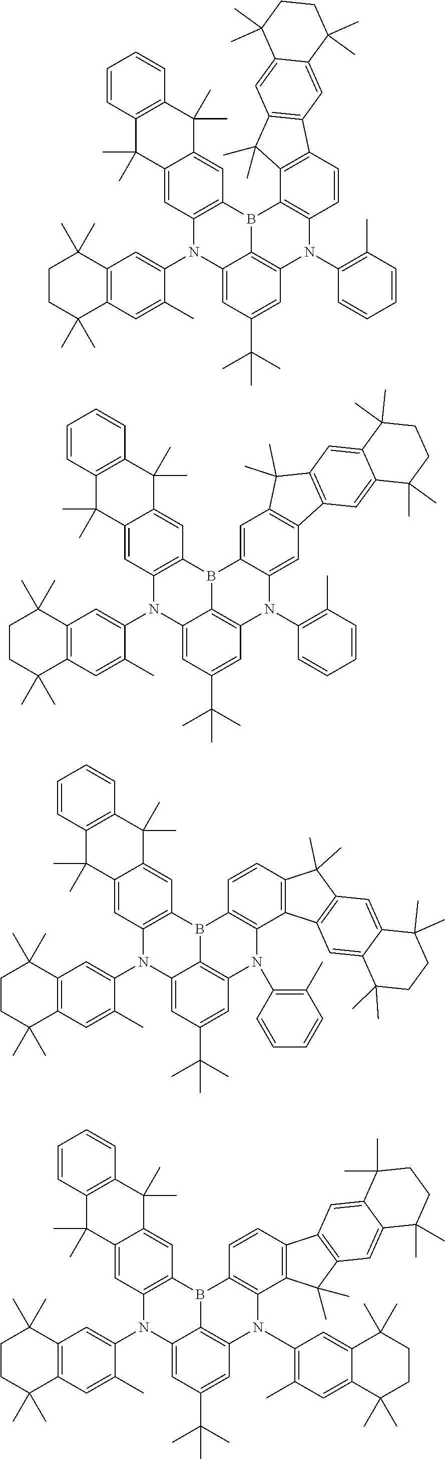

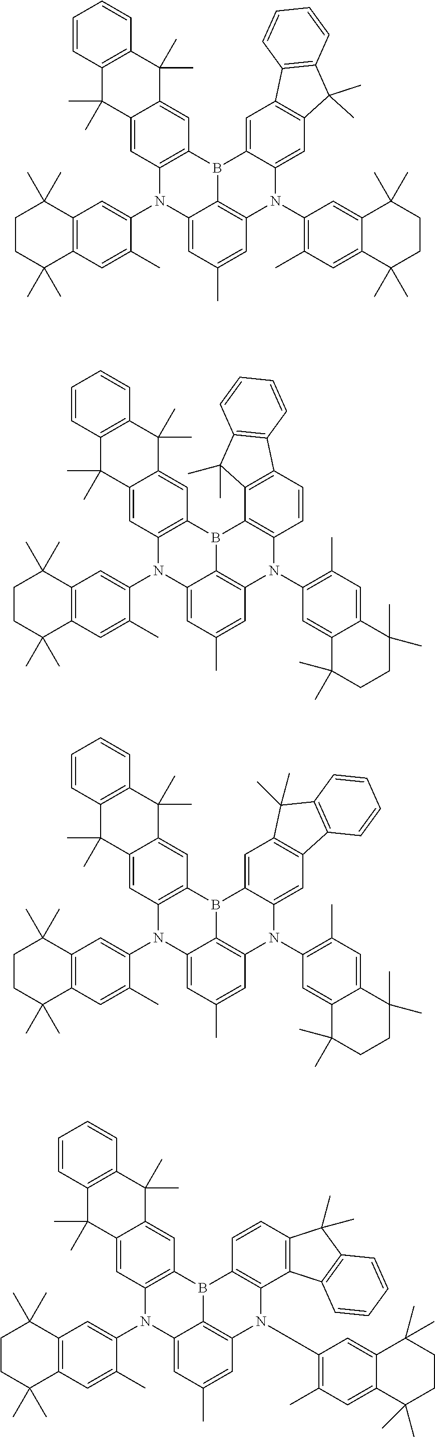

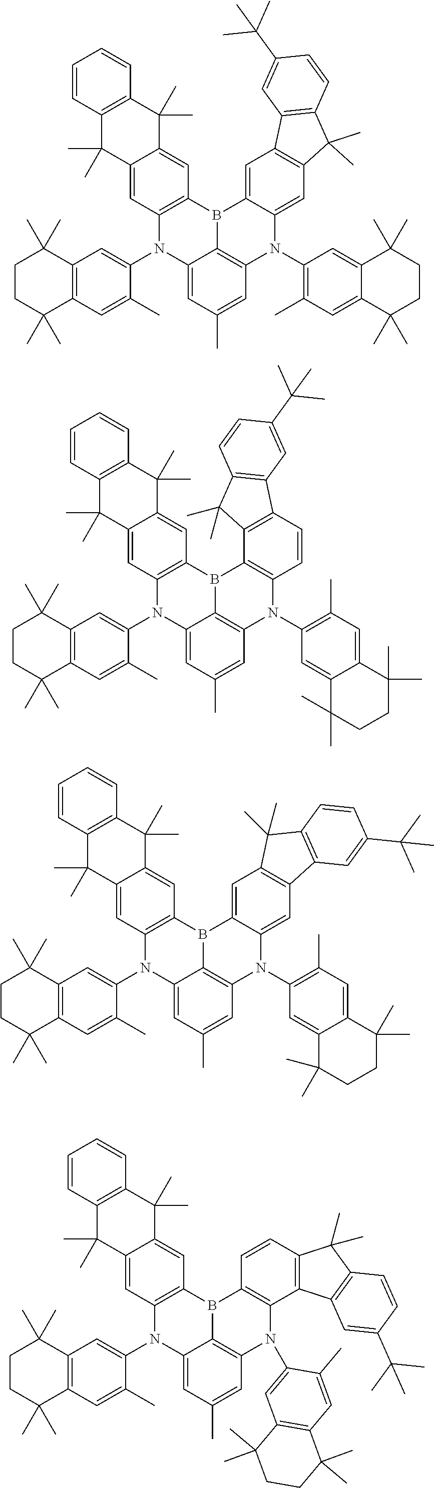

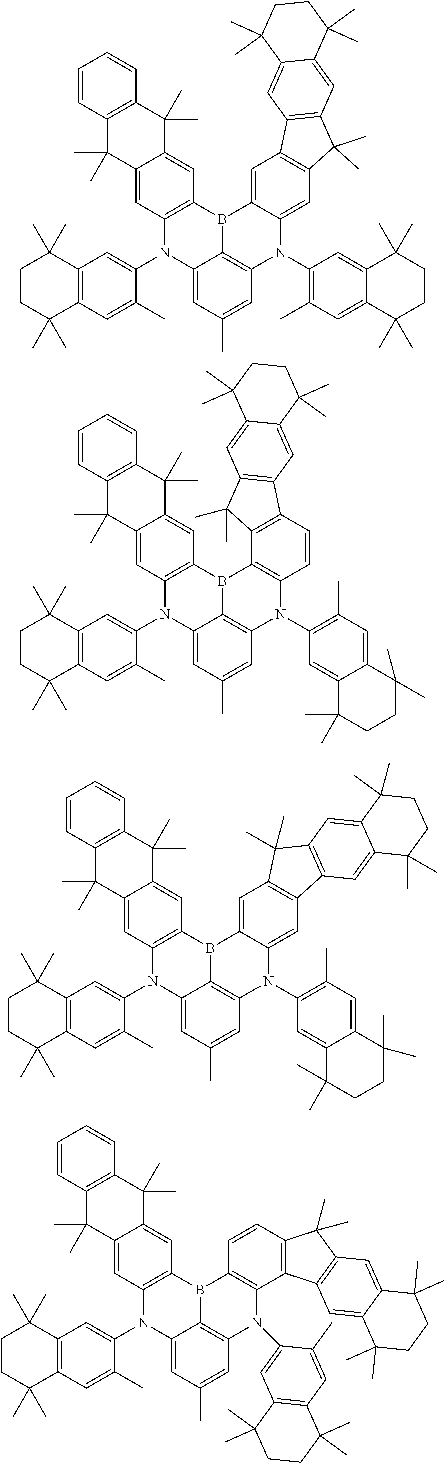

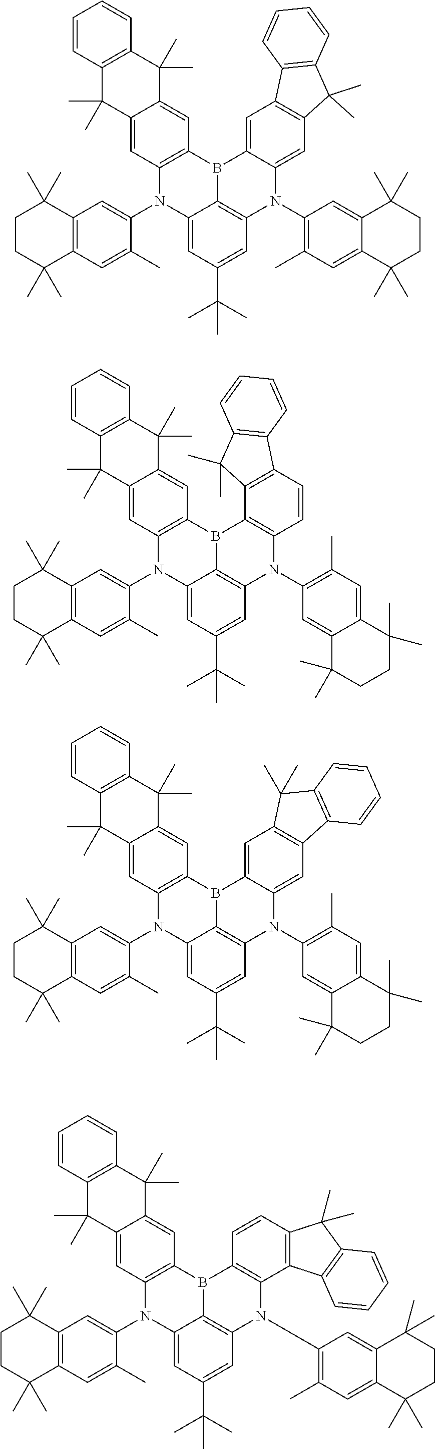

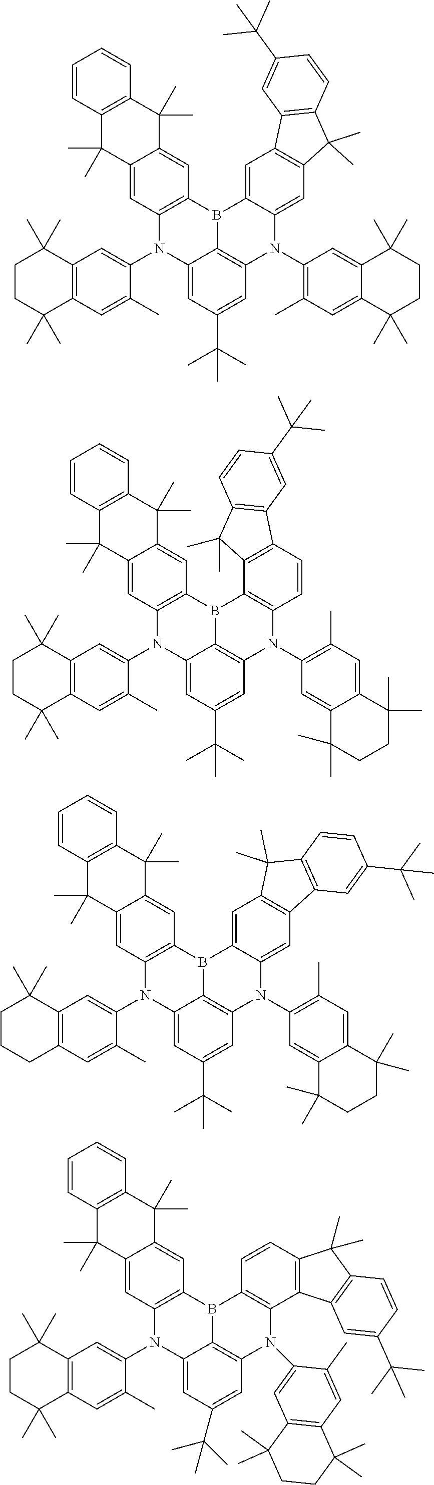

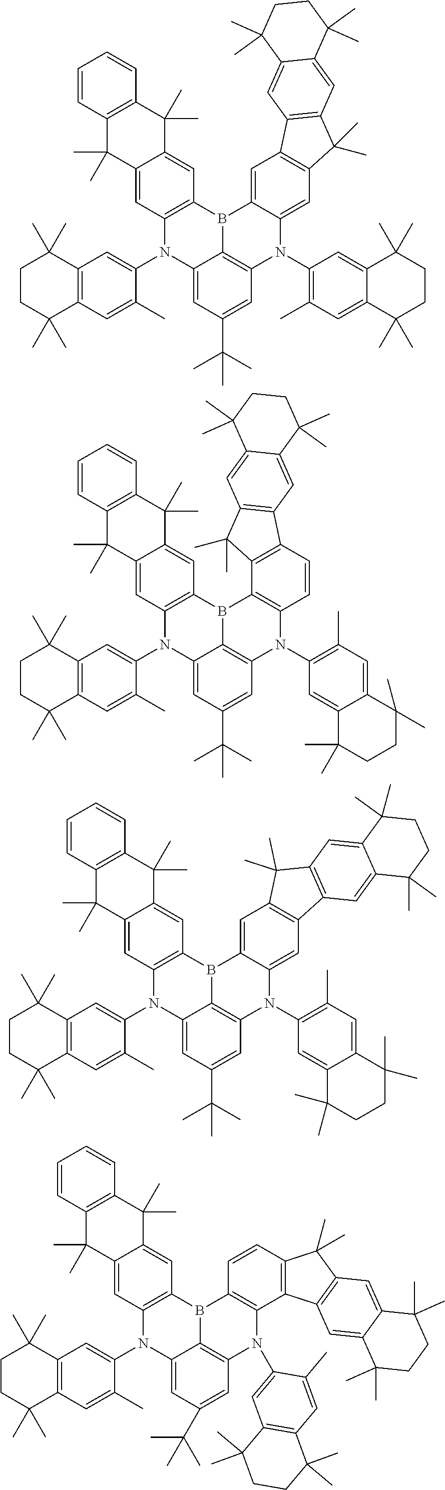

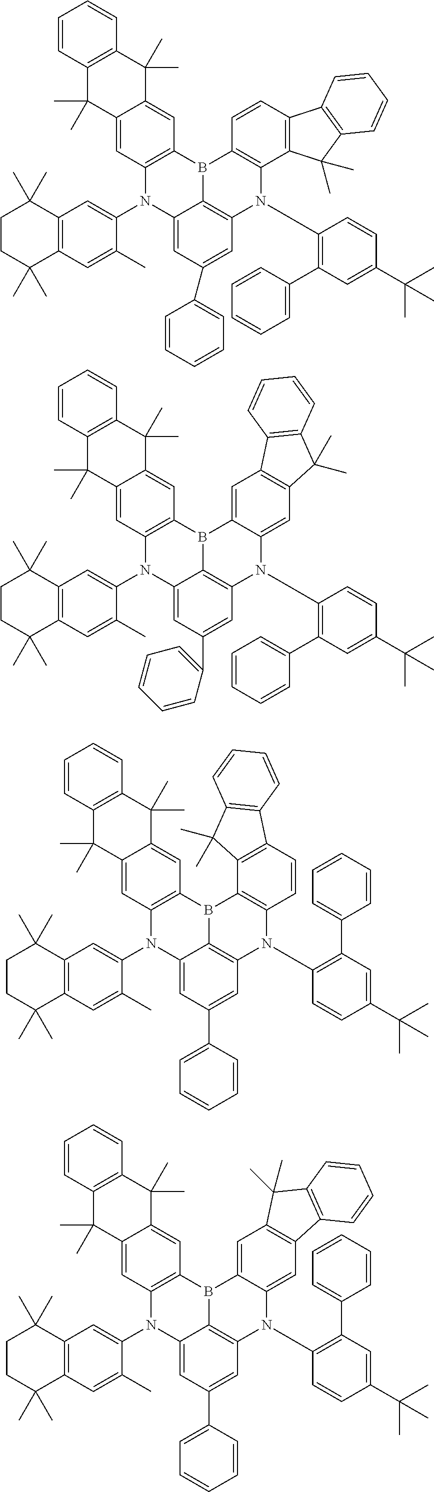

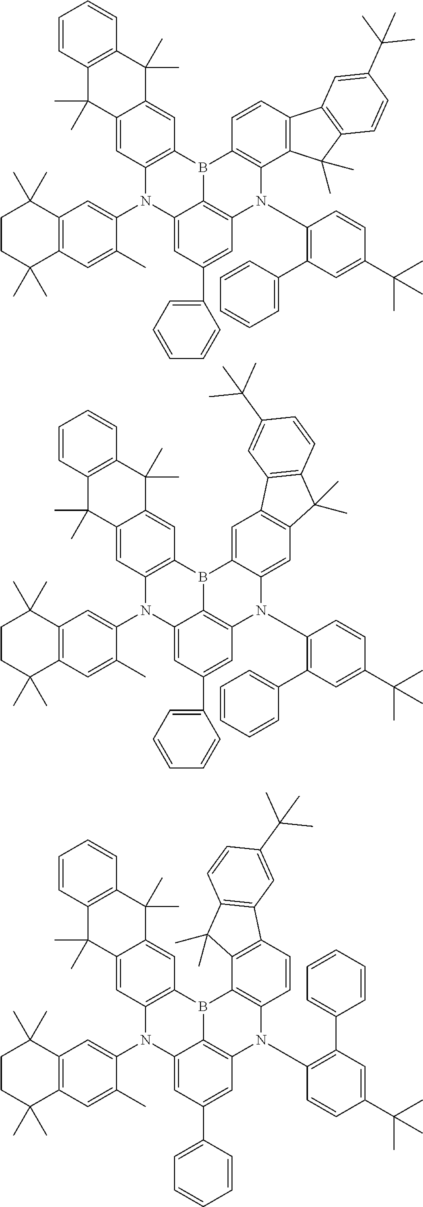

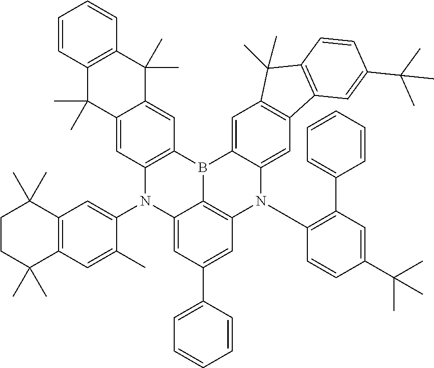 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)-c1cc(C(C)(C)C)ccc1C6(C)C)C(C)(C)c1ccccc1C4(C)C)C(C)(C)CCC2(C)C]

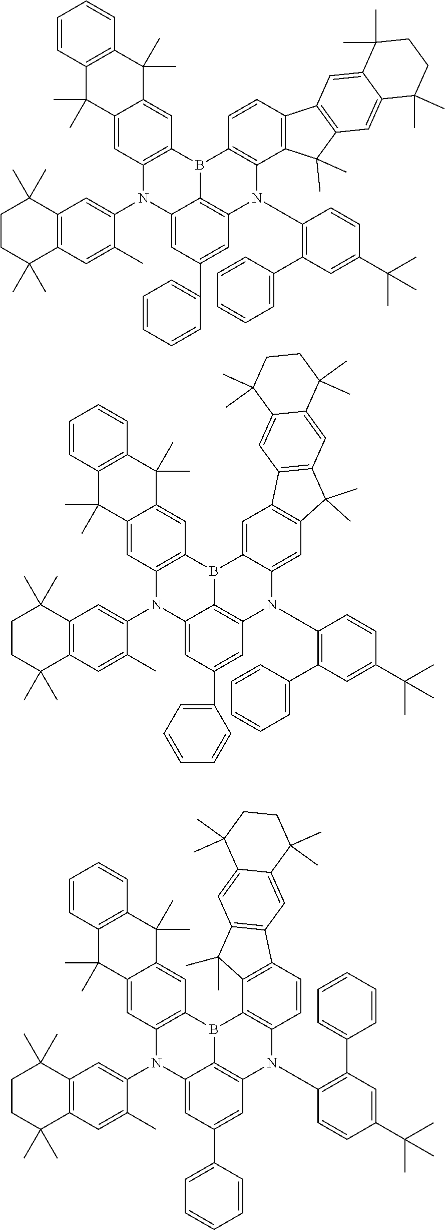

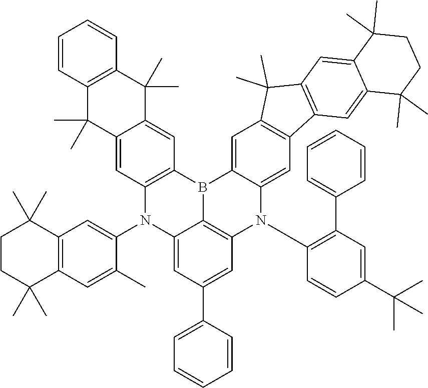 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)-c1cc3c(cc1C6(C)C)C(C)(C)CCC3(C)C)C(C)(C)c1ccccc1C4(C)C)C(C)(C)CCC2(C)C]

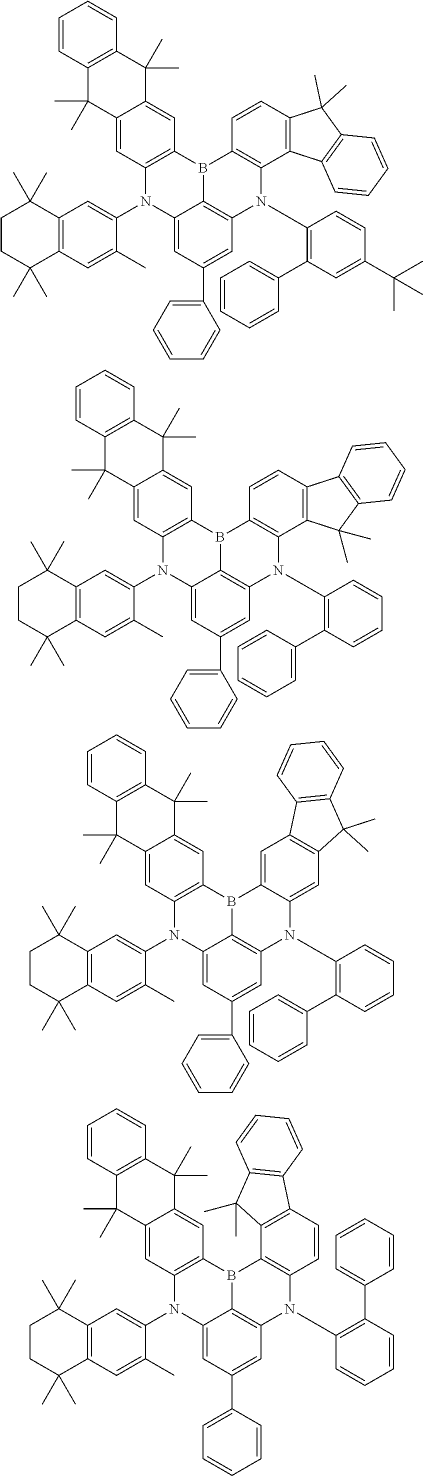

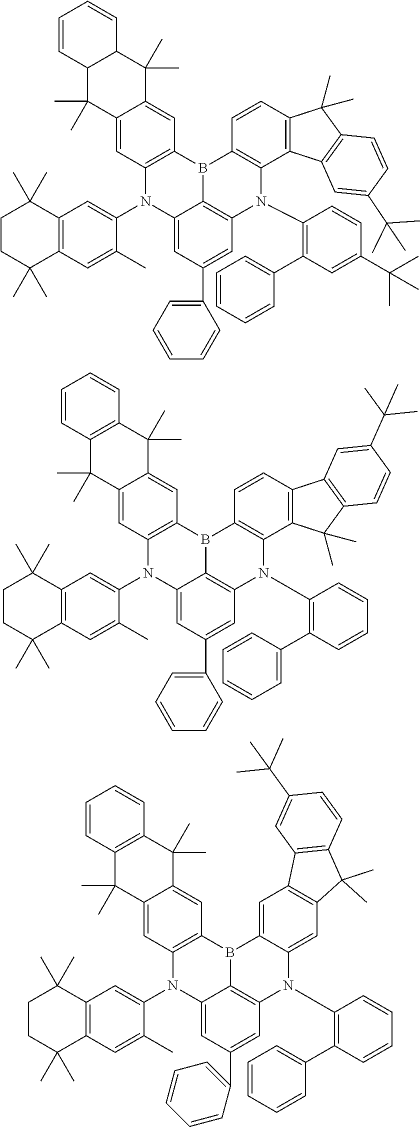

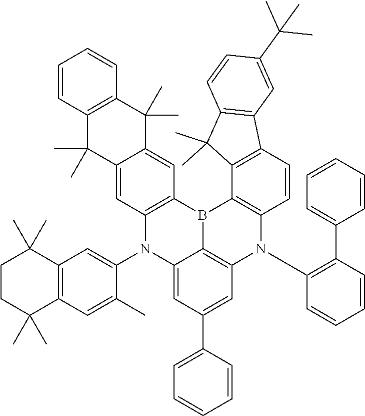 [SMILES: Cc1cc2c(cc1N1c3cc4c(cc3B3c5c1cc(-c1ccccc1)cc5N(c1ccccc1-c1ccccc1)c1ccc5c(c13)C(C)(C)c1ccc(C(C)(C)C)cc1-5)C(C)(C)c1ccccc1C4(C)C)C(C)(C)CCC2(C)C]

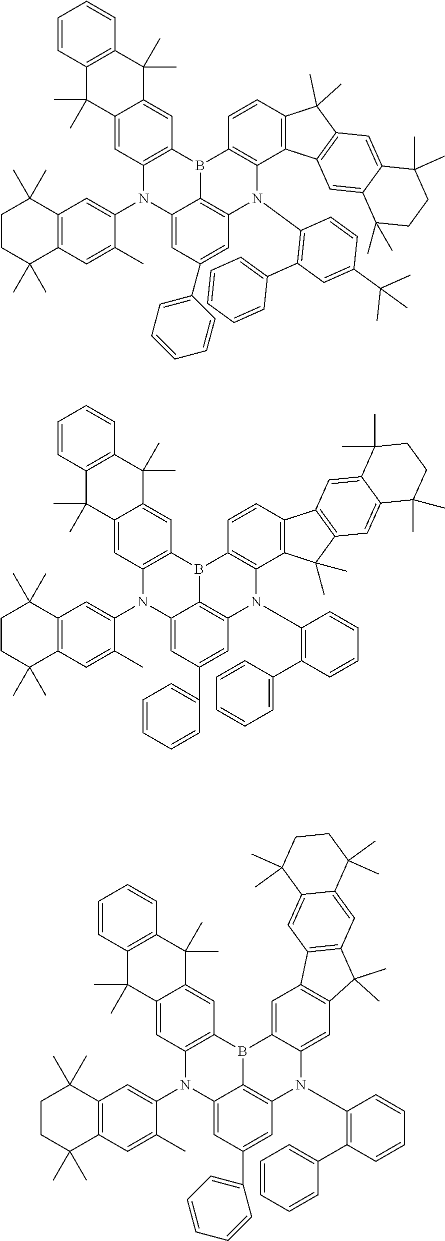 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)C(C)(C)c1cc3c(cc1-6)C(C)(C)CCC3(C)C)C(C)(C)c1ccccc1C4(C)C)C(C)(C)CCC2(C)C]

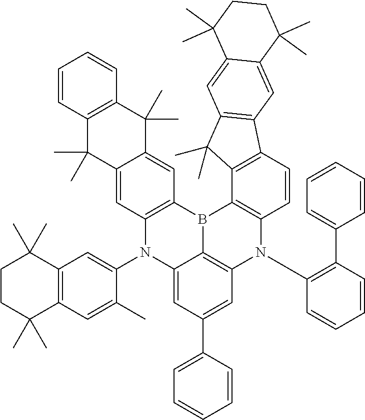 [SMILES: Cc1cc2c(cc1N1c3cc4c(cc3B3c5c1cc(-c1ccccc1)cc5N(c1ccccc1-c1ccccc1)c1ccc5c(c13)C(C)(C)c1cc3c(cc1-5)C(C)(C)CCC3(C)C)C(C)(C)c1ccccc1C4(C)C)C(C)(C)CCC2(C)C]

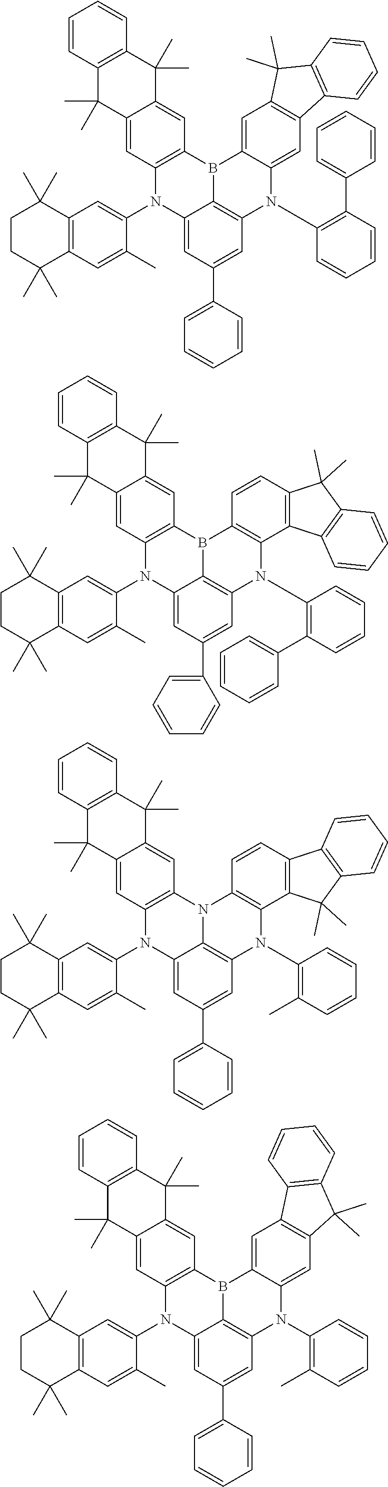

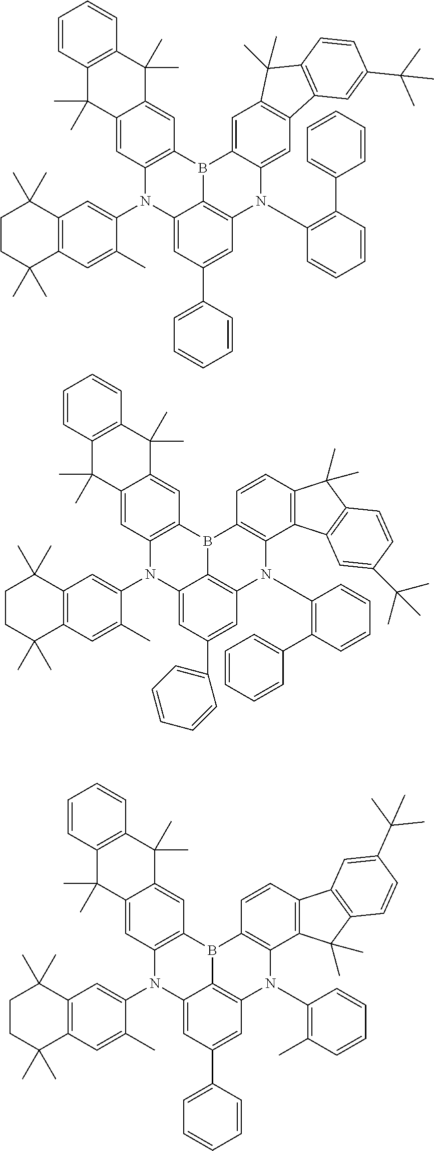 [SMILES: Cc1cc2c(cc1N1c3cc4c(cc3B3c5cc6c(cc5N(c5ccccc5-c5ccccc5)c5cc(-c7ccccc7)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5C)c5cc(-c7ccccc7)cc1c53)C(C)(C)c1ccc(C(C)(C)C)cc1-6)C(C)(C)c1ccccc1C4(C)C)C(C)(C)CCC2(C)C]

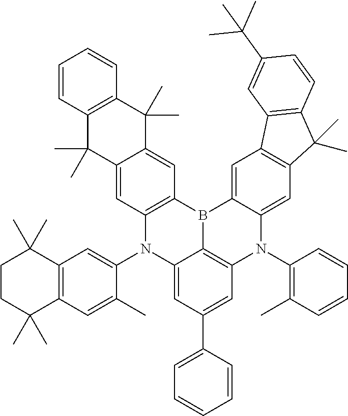 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)-c1cc(C(C)(C)C)ccc1C3(C)C]

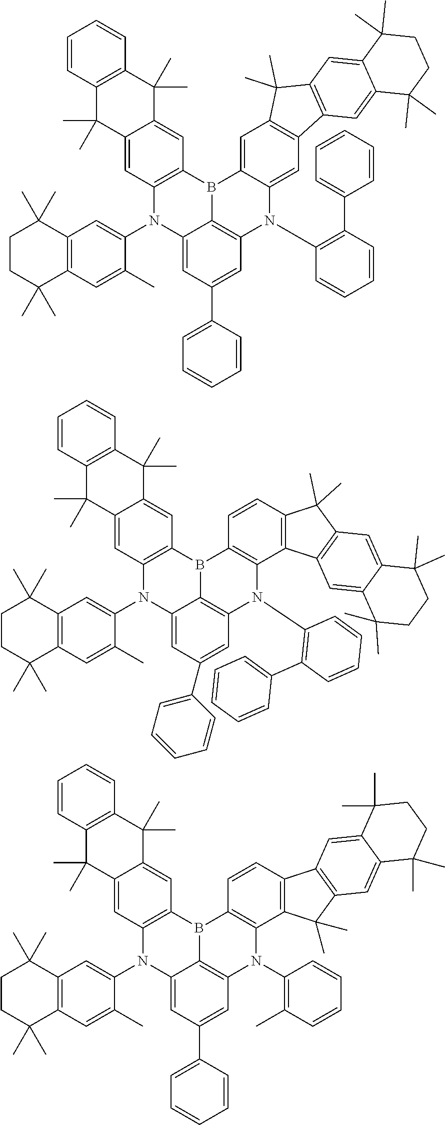 [SMILES: Cc1cc2c(cc1N1c3cc4c(cc3B3c5cc6c(cc5N(c5ccccc5-c5ccccc5)c5cc(-c7ccccc7)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5C)c5cc(-c7ccccc7)cc1c53)C(C)(C)c1cc3c(cc1-6)C(C)(C)CCC3(C)C)C(C)(C)c1ccccc1C4(C)C)C(C)(C)CCC2(C)C]

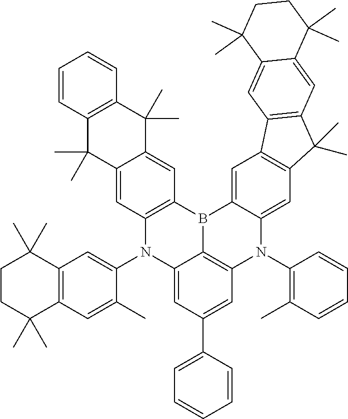 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)-c1cc2c(cc1C3(C)C)C(C)(C)CCC2(C)C]

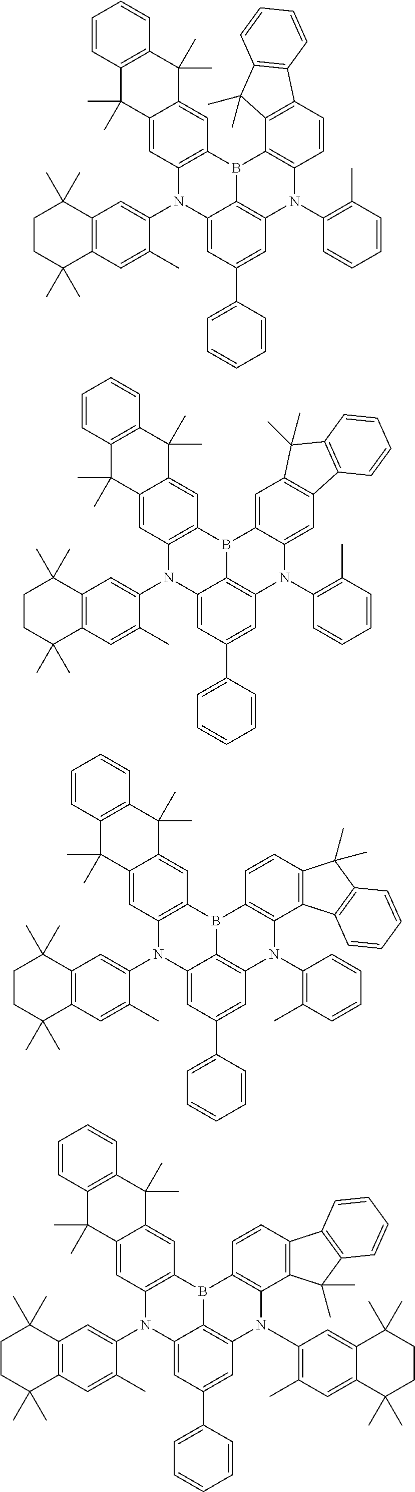

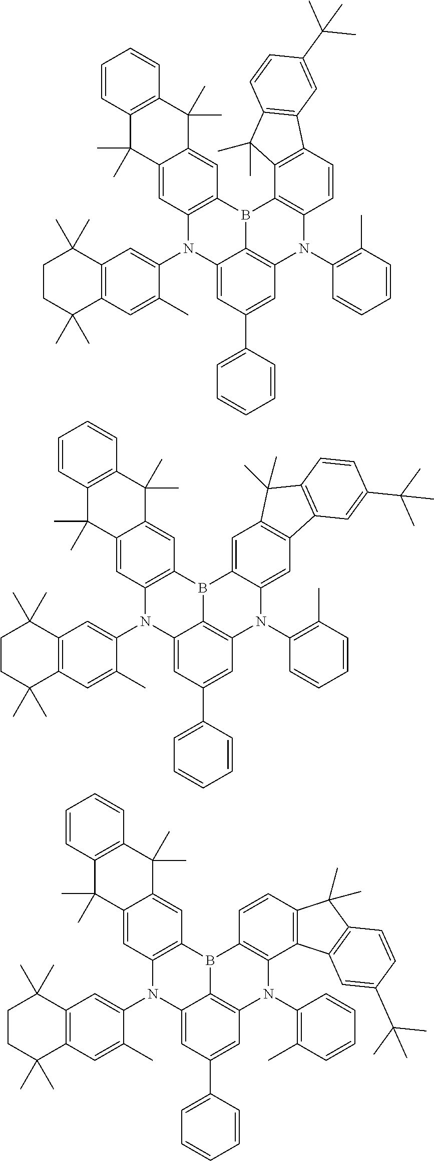 [SMILES: Cc1cc2c(cc1N1c3cc4c(cc3B3c5c1cc(-c1ccccc1)cc5N(c1ccccc1C)c1ccc5c(c13)C(C)(C)c1ccc(C(C)(C)C)cc1-5)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)C(C)(C)c1ccc(C(C)(C)C)cc1-3 ; Cc1cc2c(cc1N1c3cc4c(cc3B3c5ccc6c(c5N(c5ccccc5C)c5cc(-c7ccccc7)cc1c53)-c1cc(C(C)(C)C)ccc1C6(C)C)C(C)(C)c1ccccc1C4(C)C)C(C)(C)CCC2(C)C]

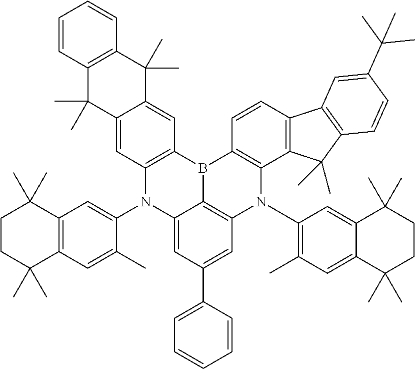 [SMILES: Cc1cc2c(cc1N1c3cc4c(cc3B3c5ccc6c(c5N(c5cc7c(cc5C)C(C)(C)CCC7(C)C)c5cc(-c7ccccc7)cc1c53)C(C)(C)c1ccc(C(C)(C)C)cc1-6)C(C)(C)c1ccccc1C4(C)C)C(C)(C)CCC2(C)C]

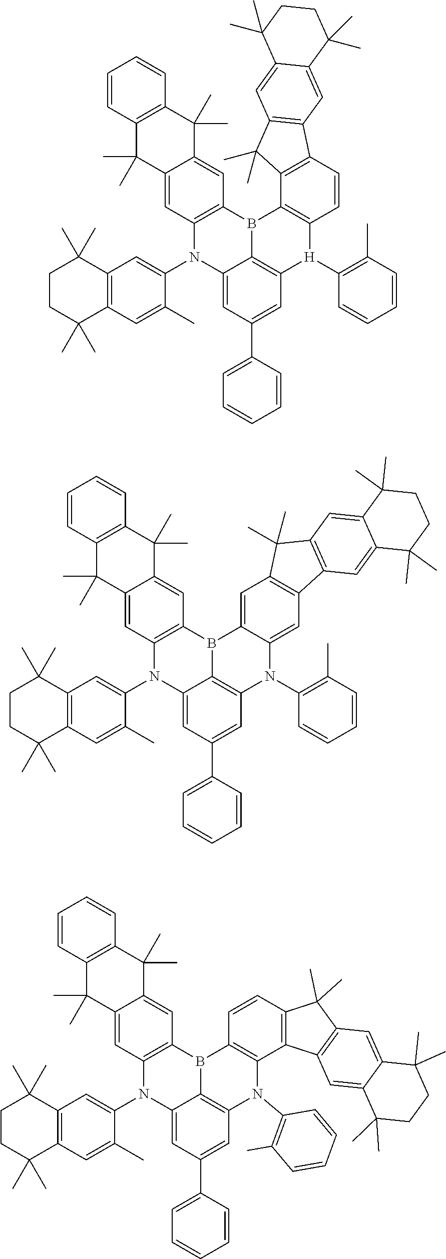

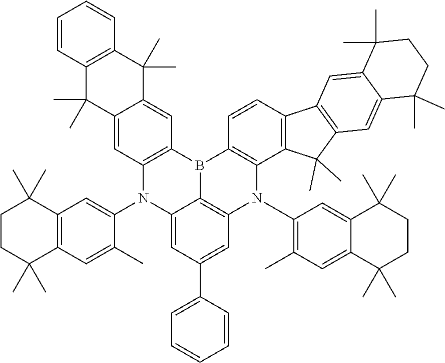 [SMILES: Cc1cc2c(cc1N1c3cc4c(cc3B3c5ccc6c(c5N(c5cc7c(cc5C)C(C)(C)CCC7(C)C)c5cc(-c7ccccc7)cc1c53)C(C)(C)c1cc3c(cc1-6)C(C)(C)CCC3(C)C)C(C)(C)c1ccccc1C4(C)C)C(C)(C)CCC2(C)C]

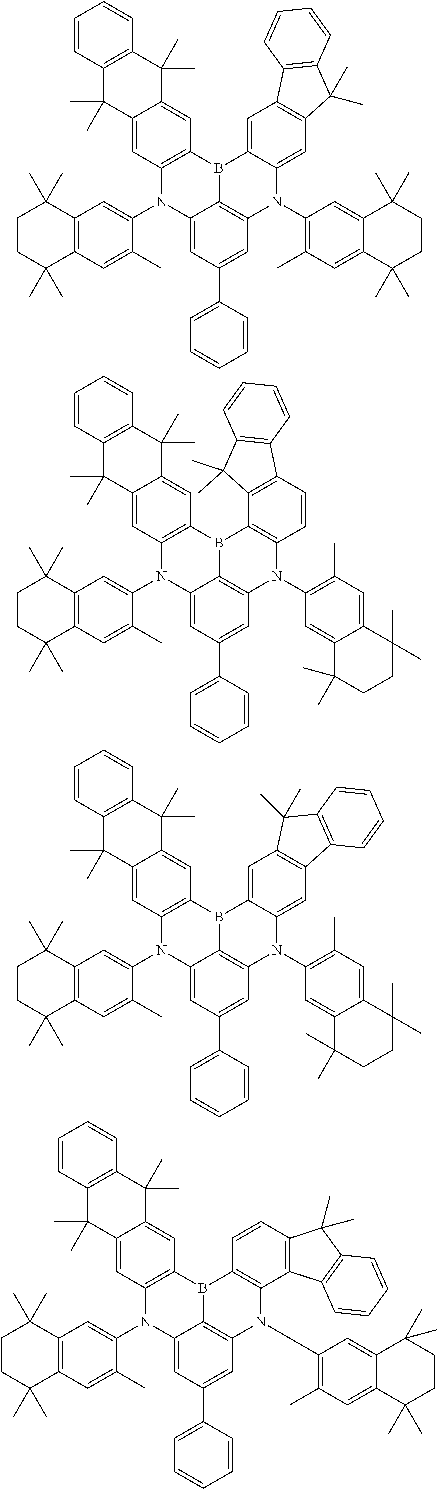

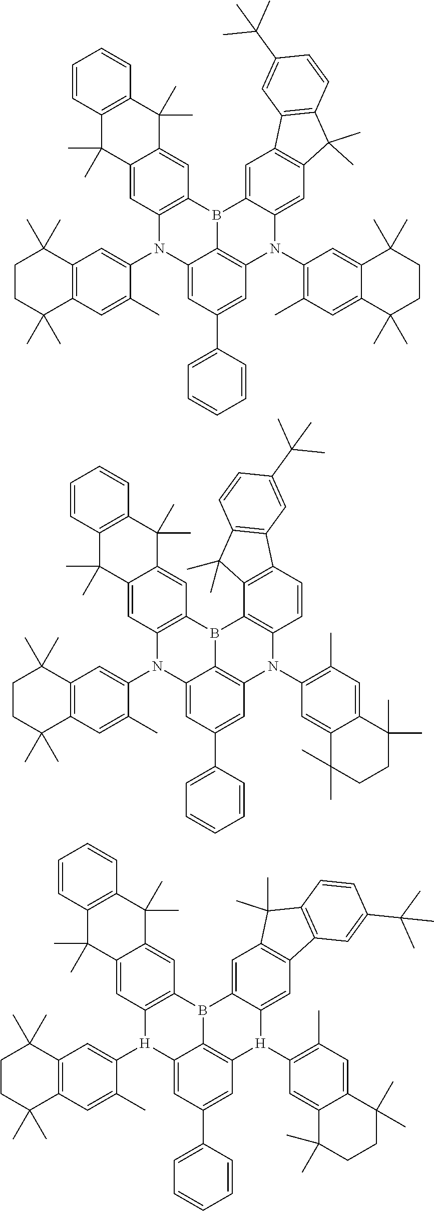

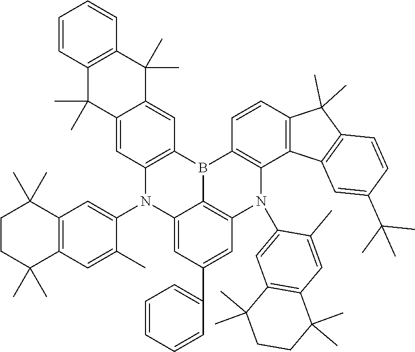 [SMILES: Cc1cc2c(cc1N1c3cc4c(cc3B3c5ccc6c(c5N(c5cc7c(cc5C)C(C)(C)CCC7(C)C)c5cc(-c7ccccc7)cc1c53)-c1cc(C(C)(C)C)ccc1C6(C)C)C(C)(C)c1ccccc1C4(C)C)C(C)(C)CCC2(C)C]

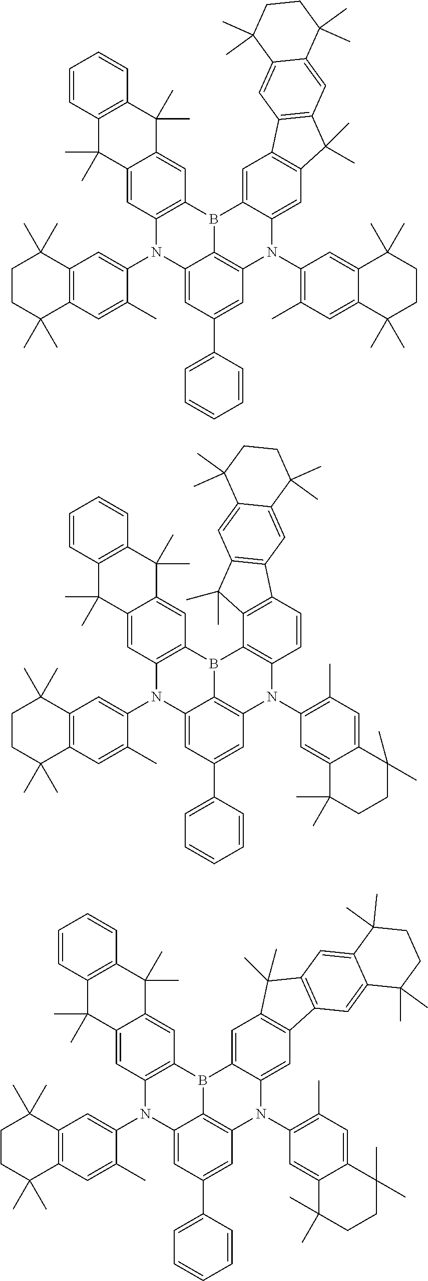

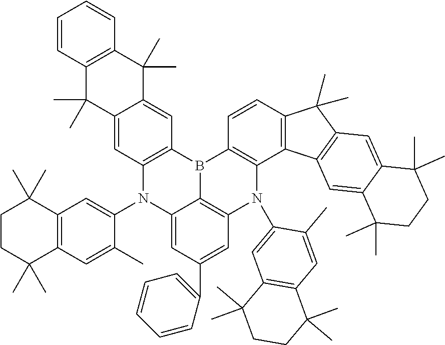 [SMILES: Cc1cc2c(cc1N1c3cc4c(cc3B3c5ccc6c(c5N(c5cc7c(cc5C)C(C)(C)CCC7(C)C)c5cc(-c7ccccc7)cc1c53)-c1cc3c(cc1C6(C)C)C(C)(C)CCC3(C)C)C(C)(C)c1ccccc1C4(C)C)C(C)(C)CCC2(C)C]

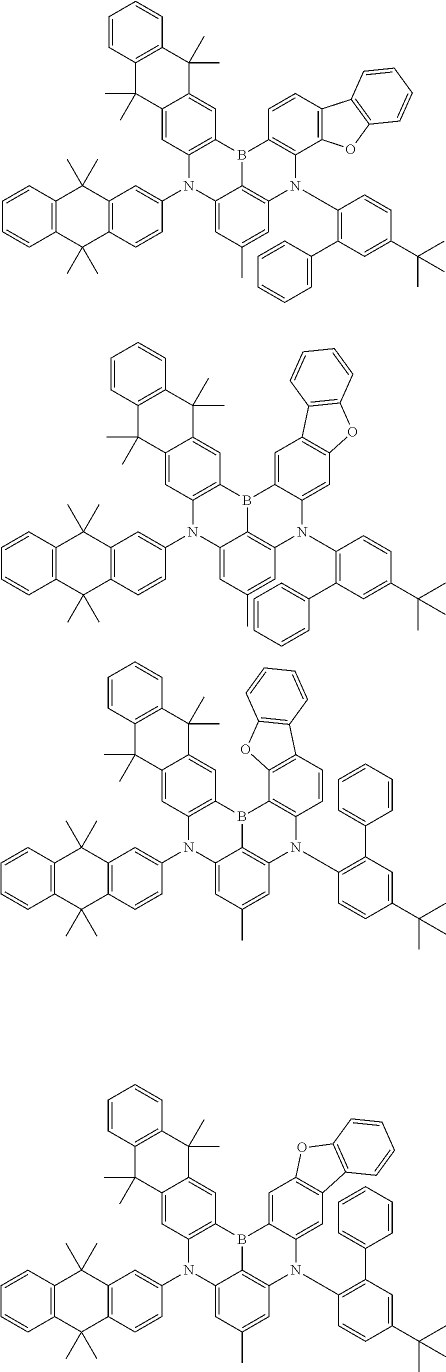

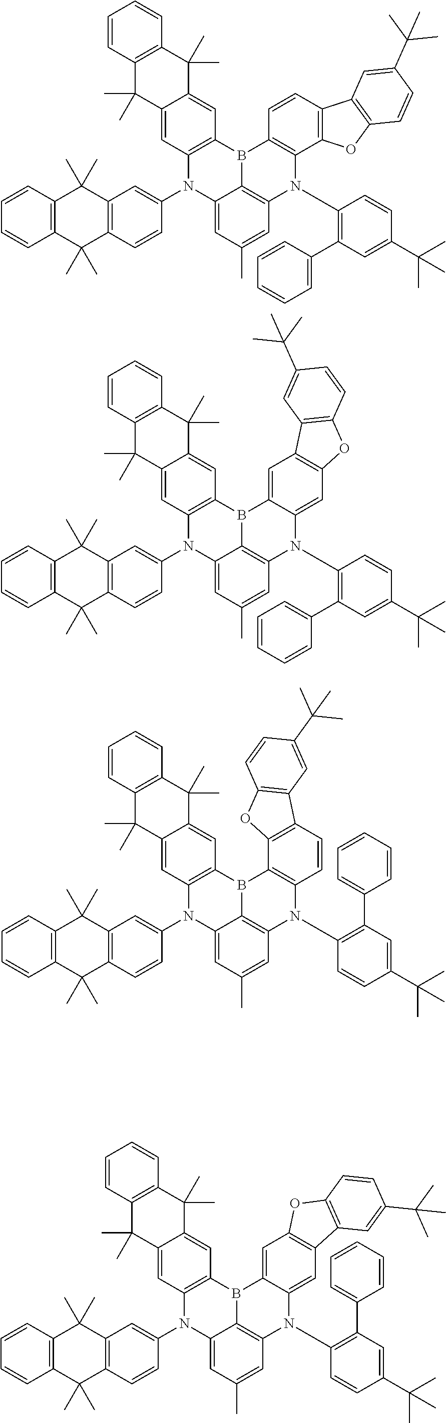

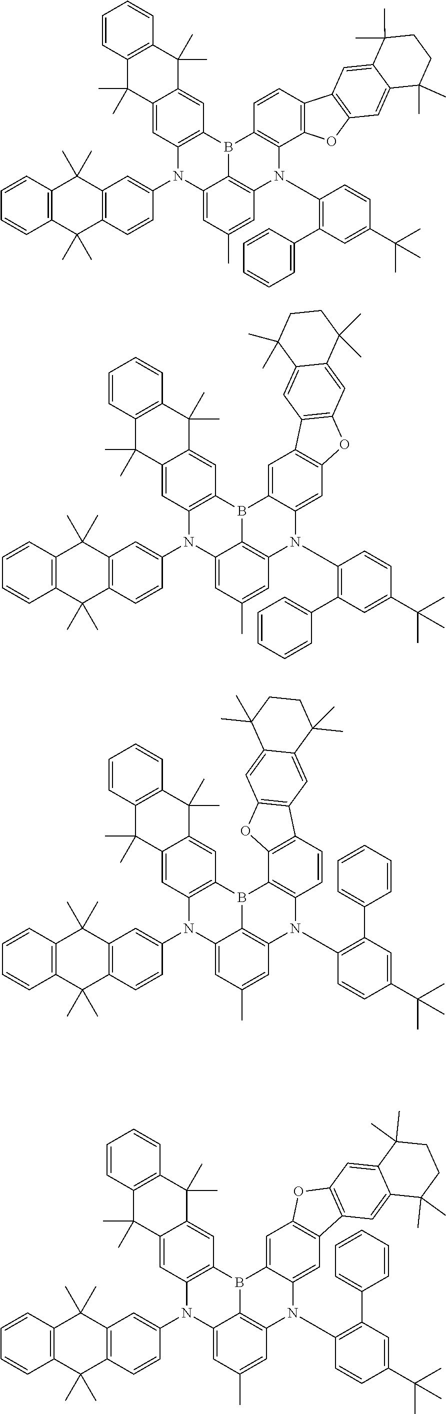

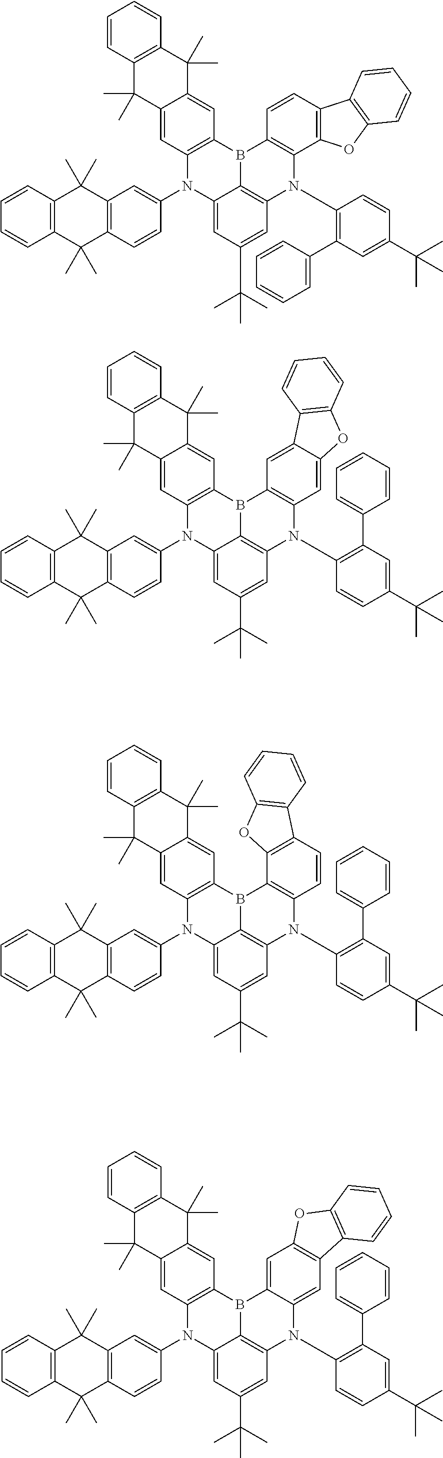

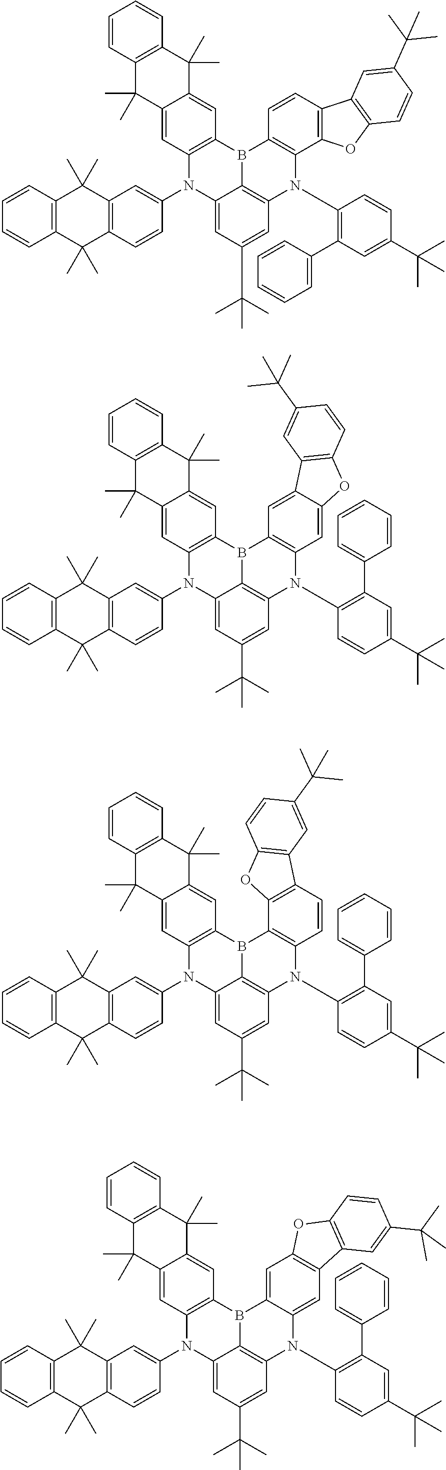

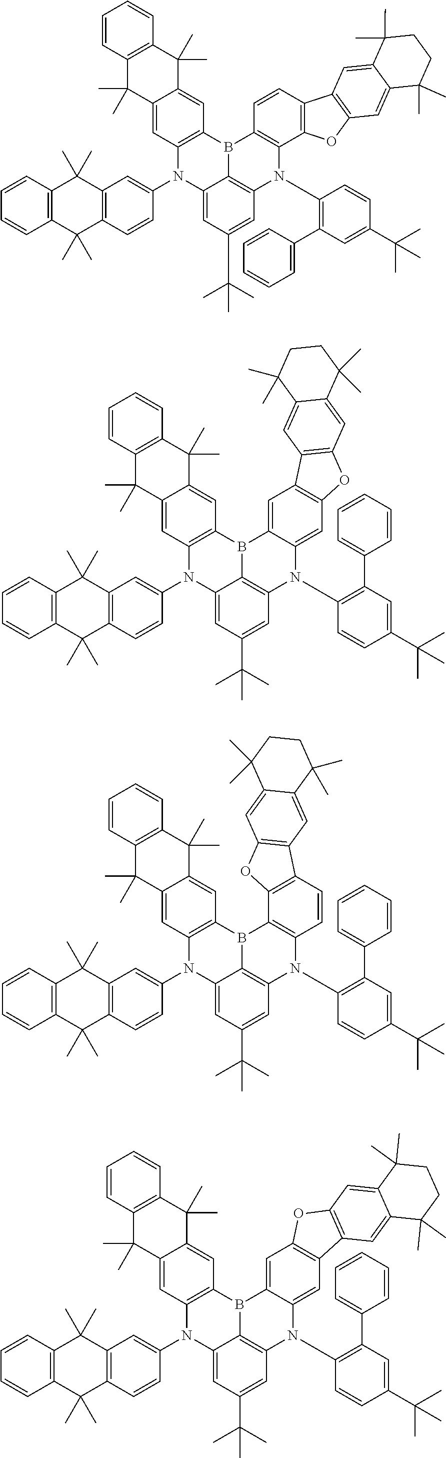

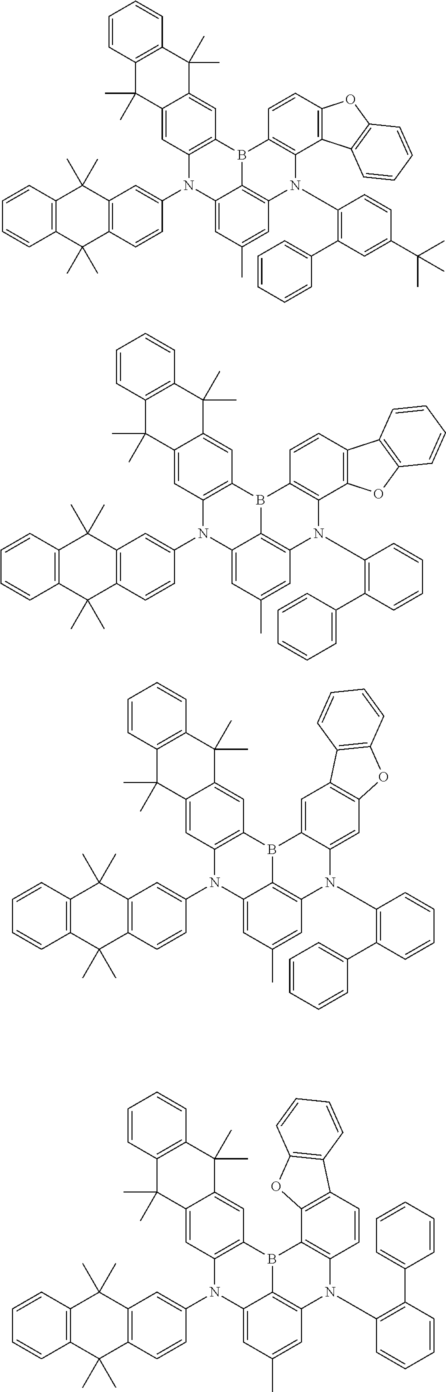

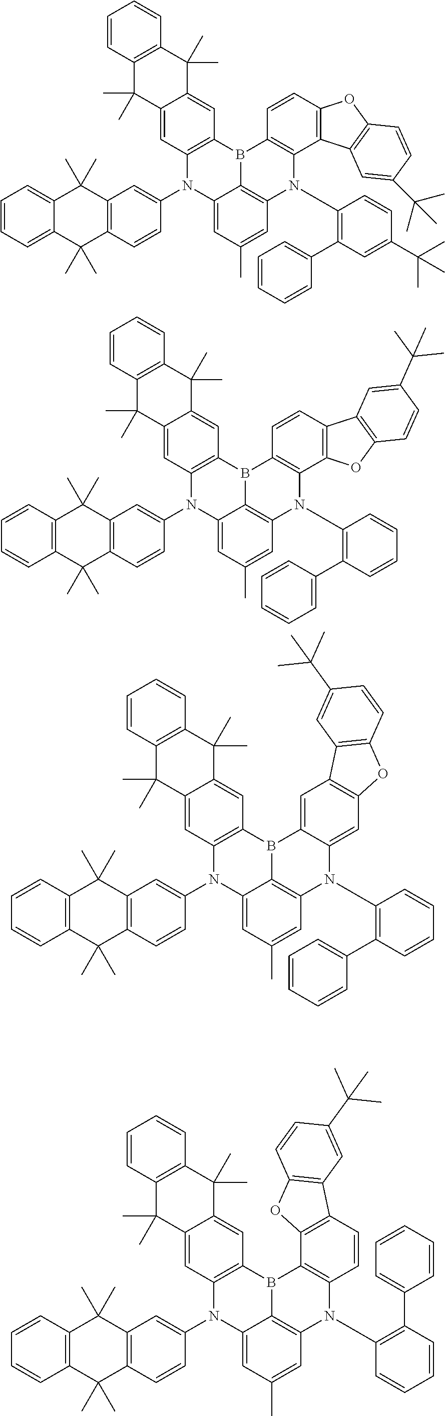

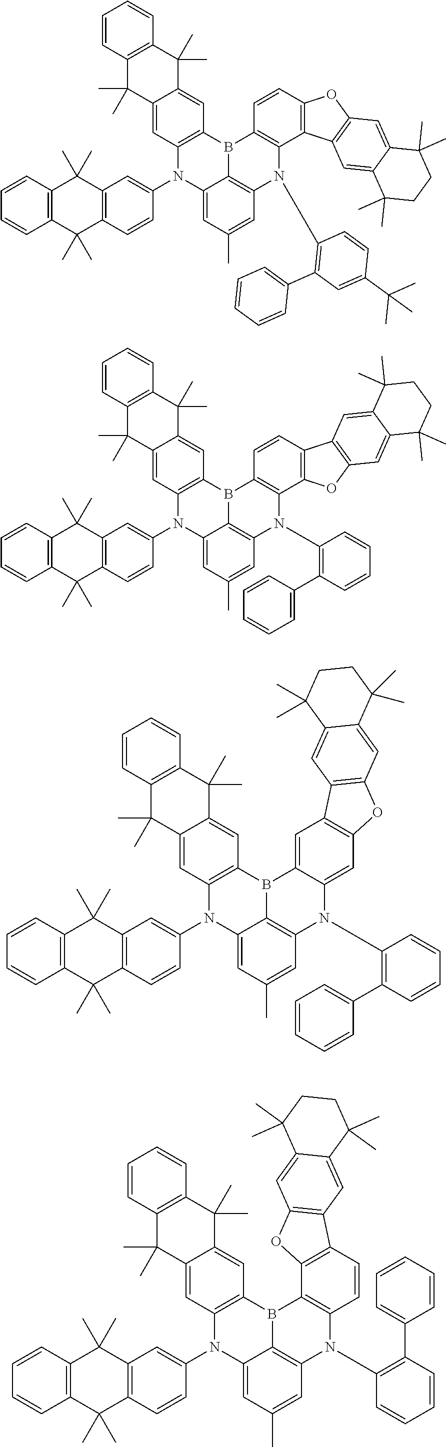

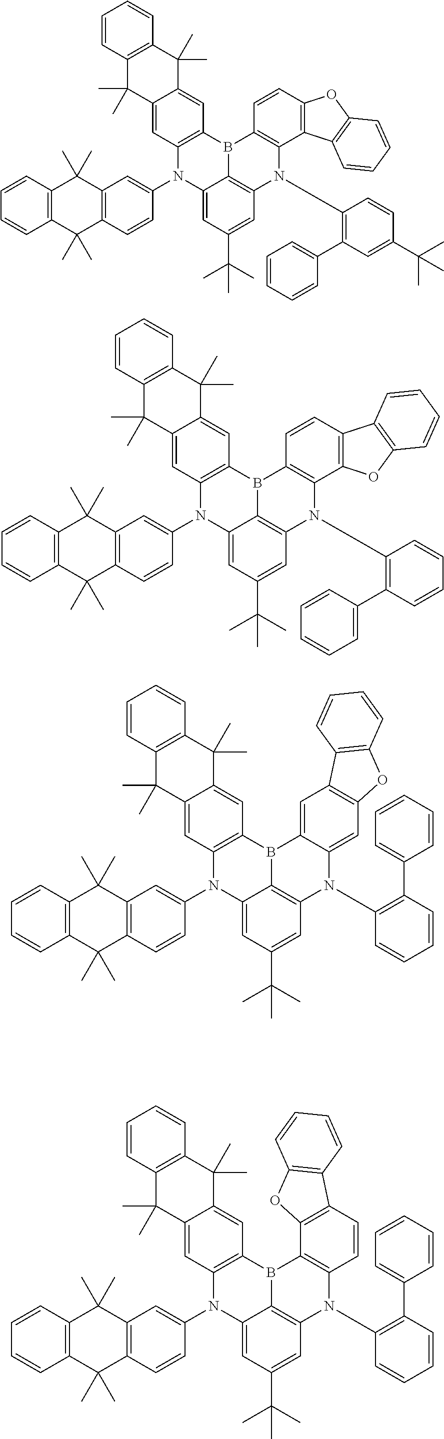

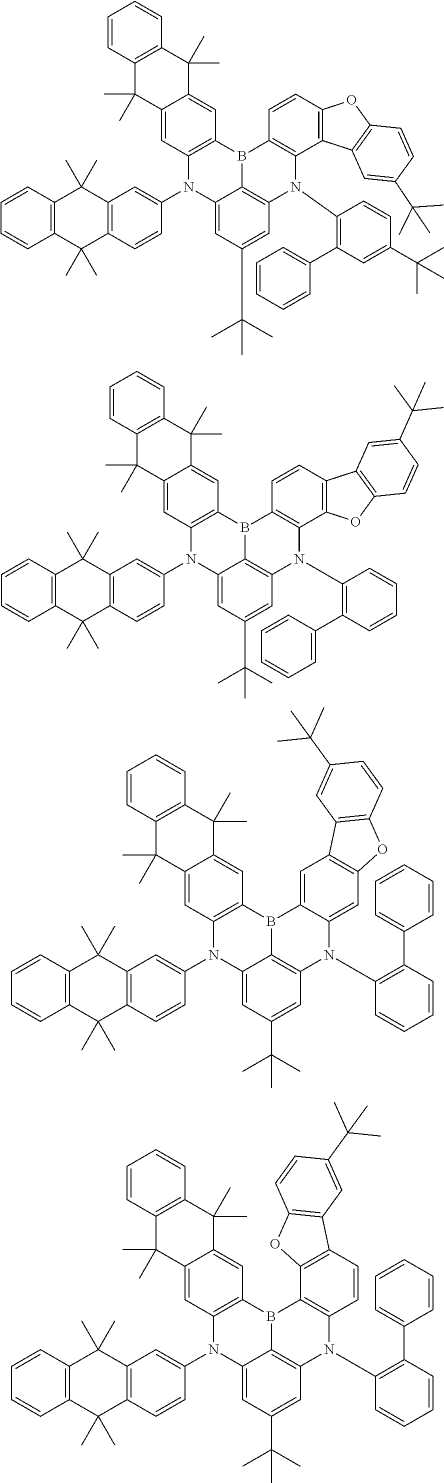

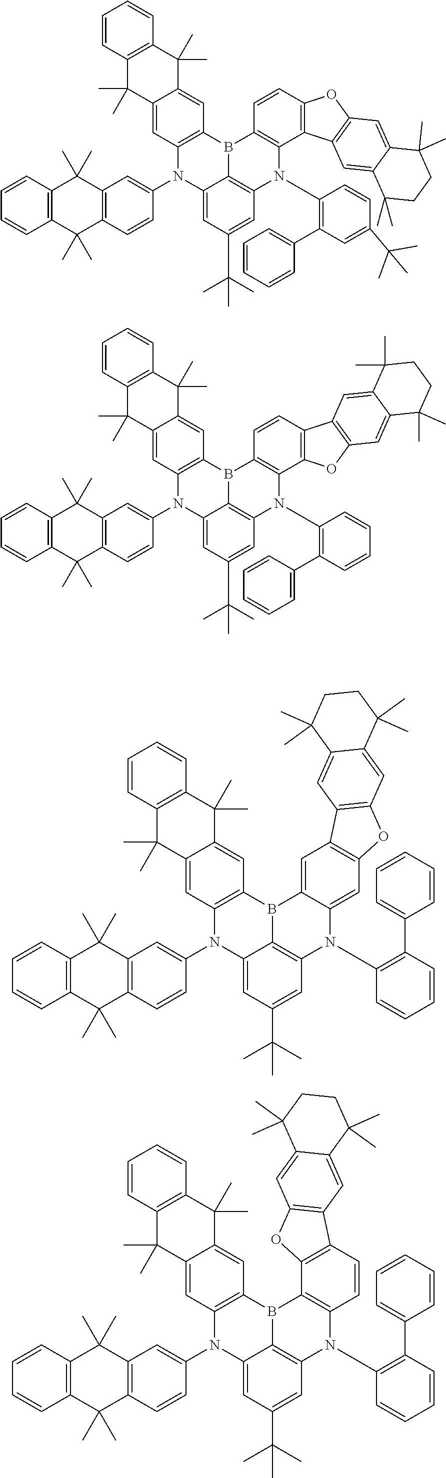

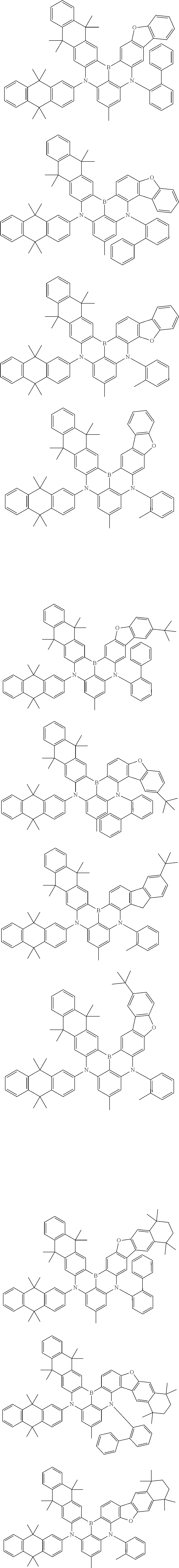

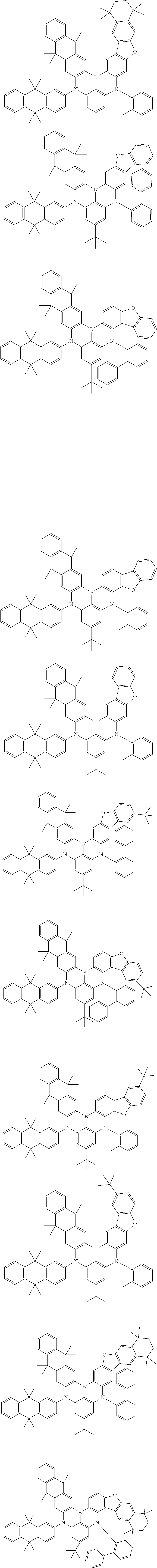

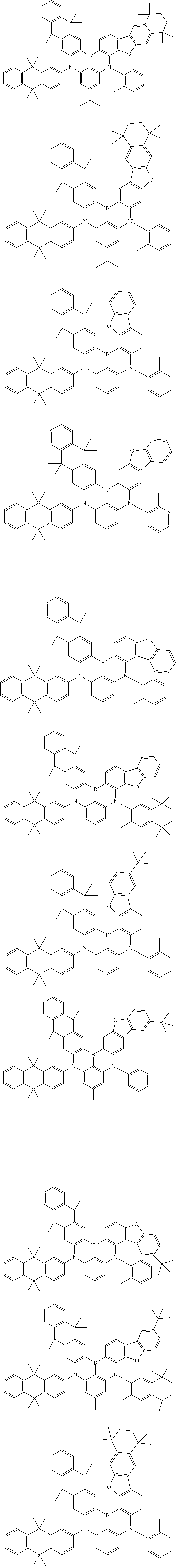

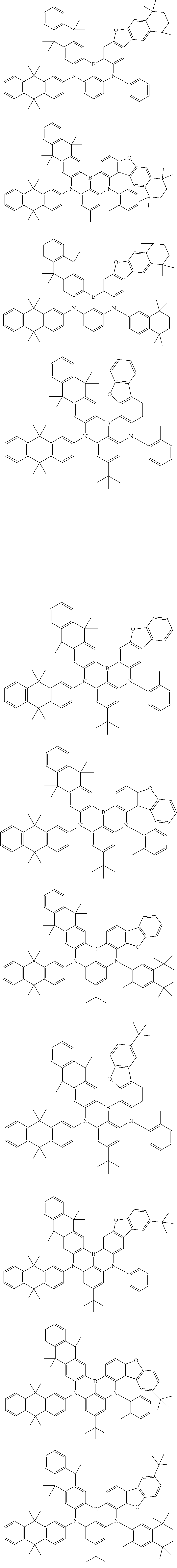

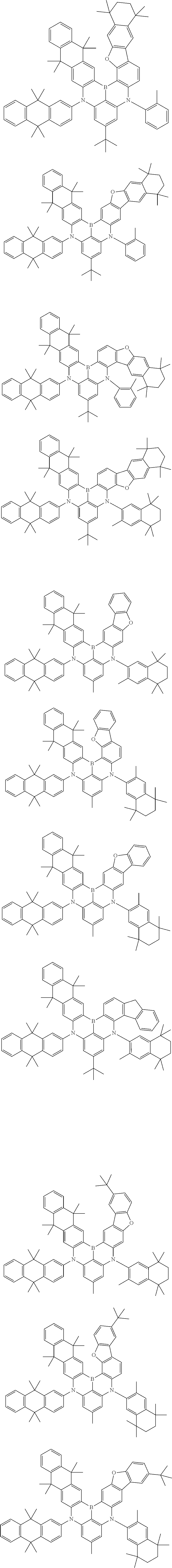

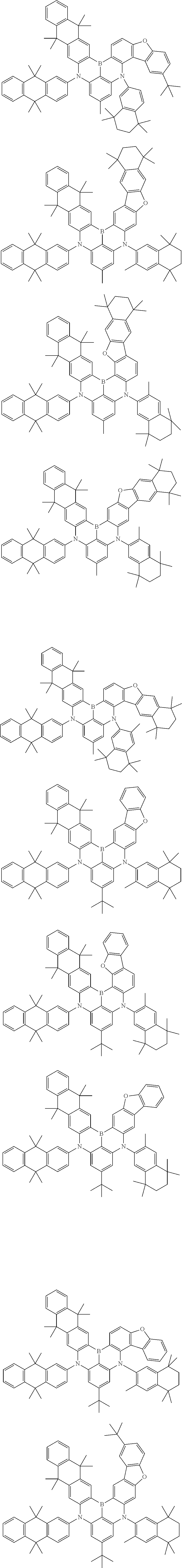

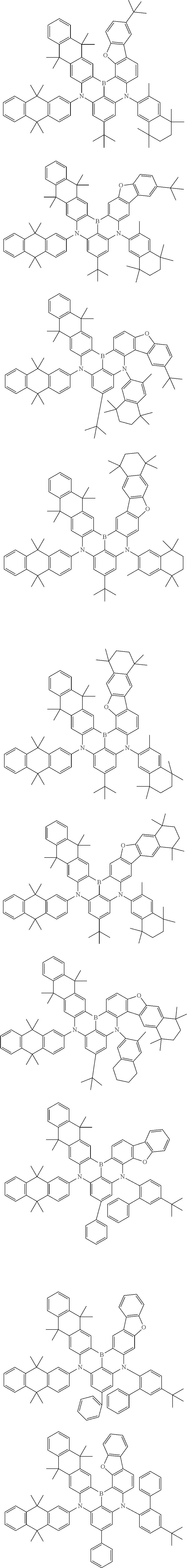

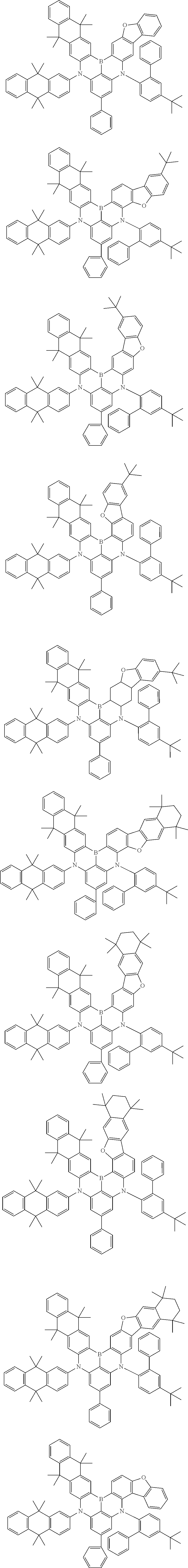

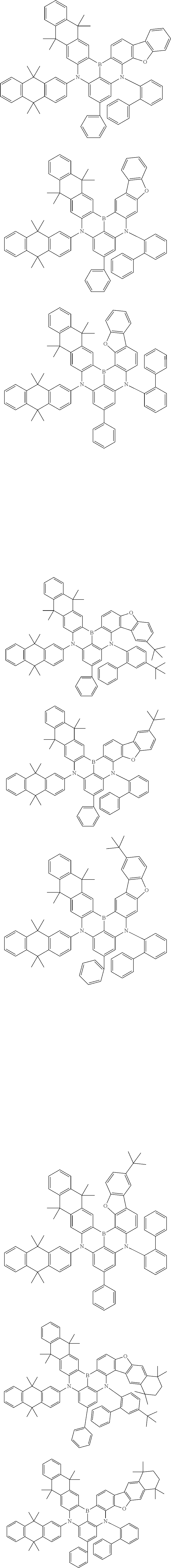

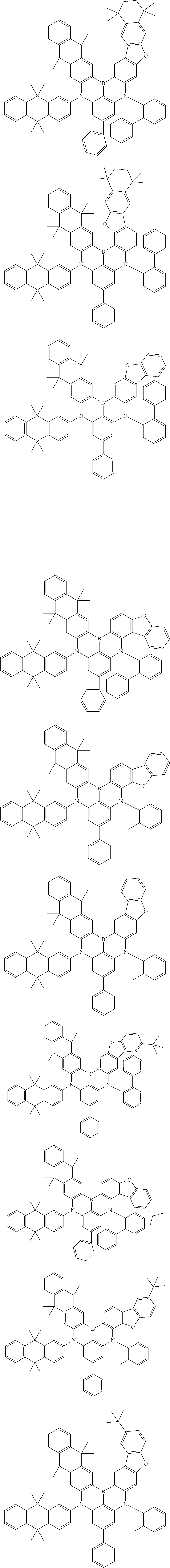

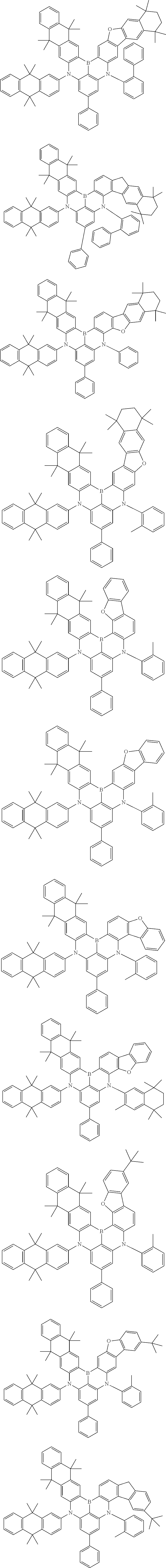

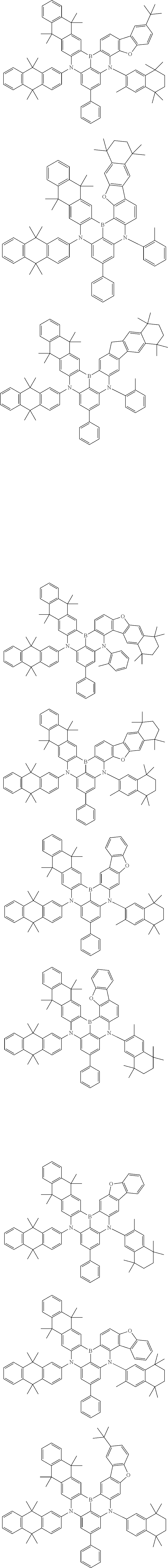

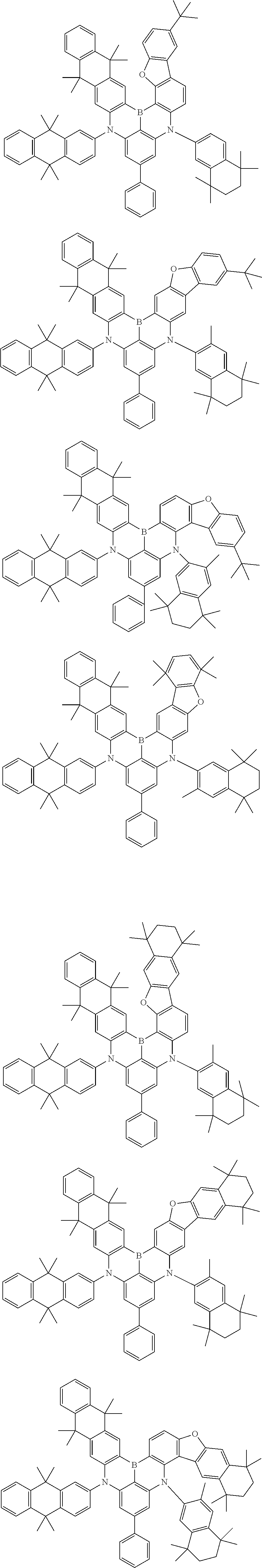

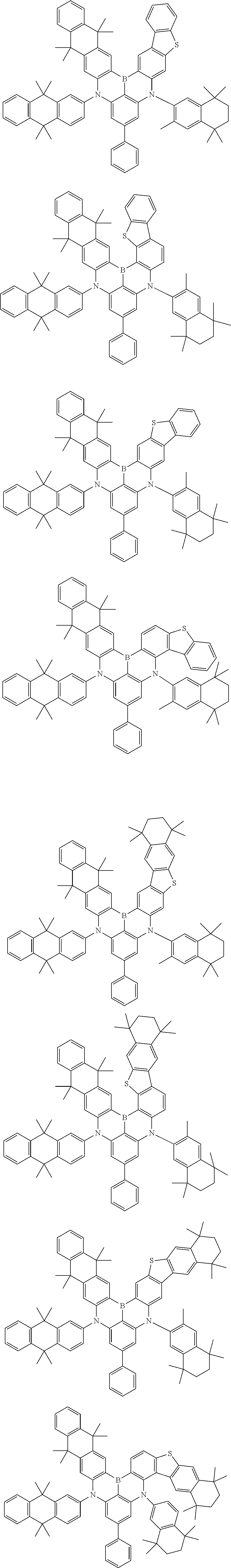

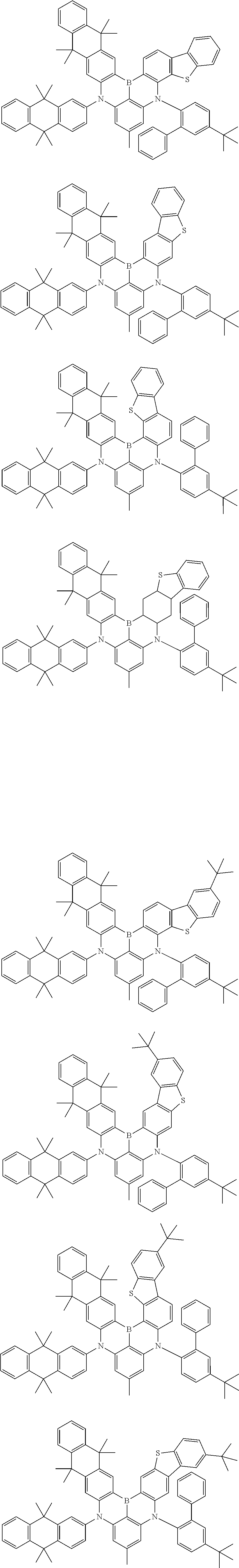

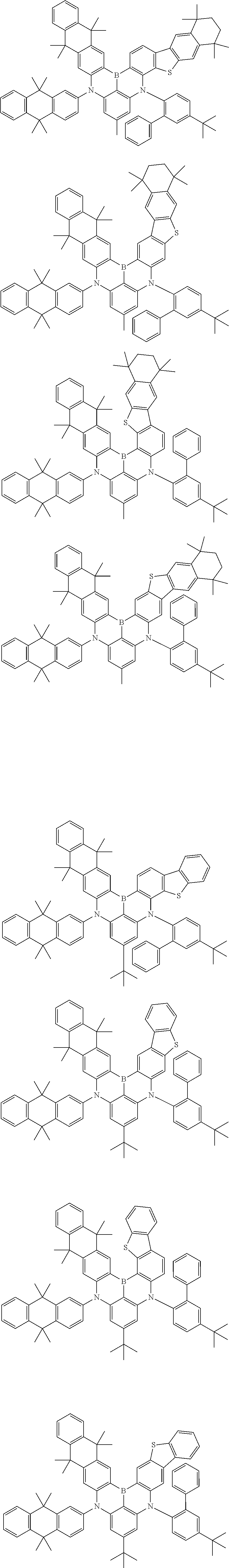

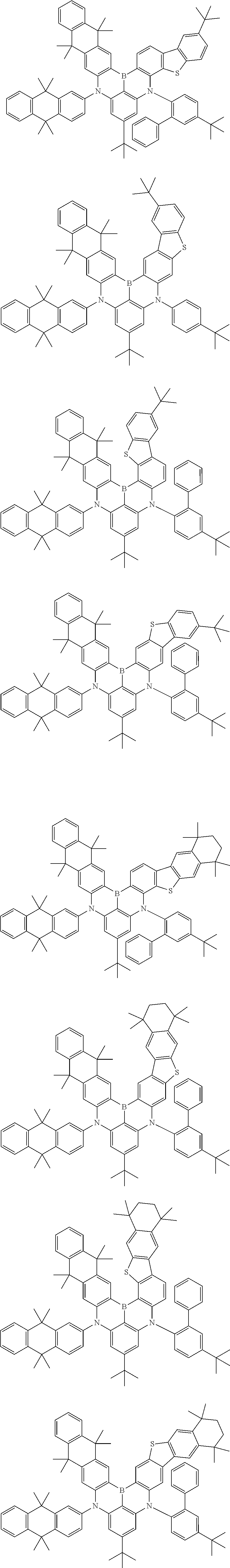

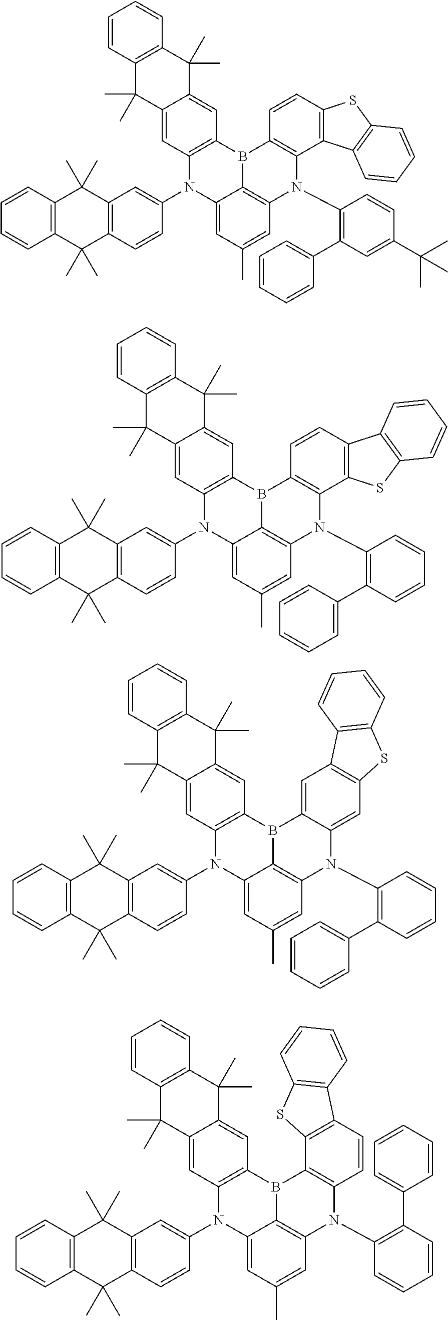

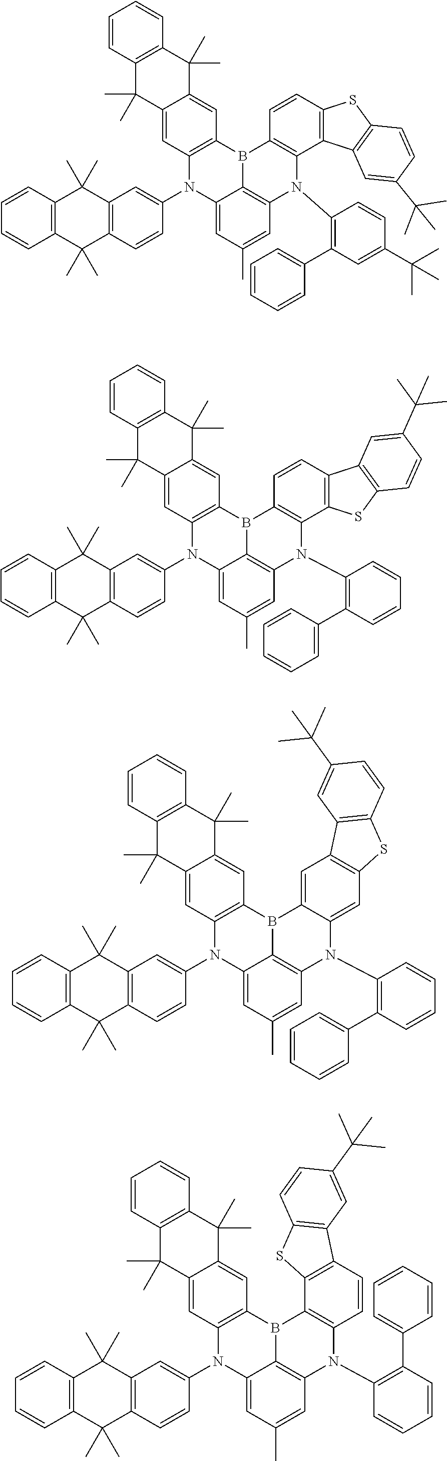

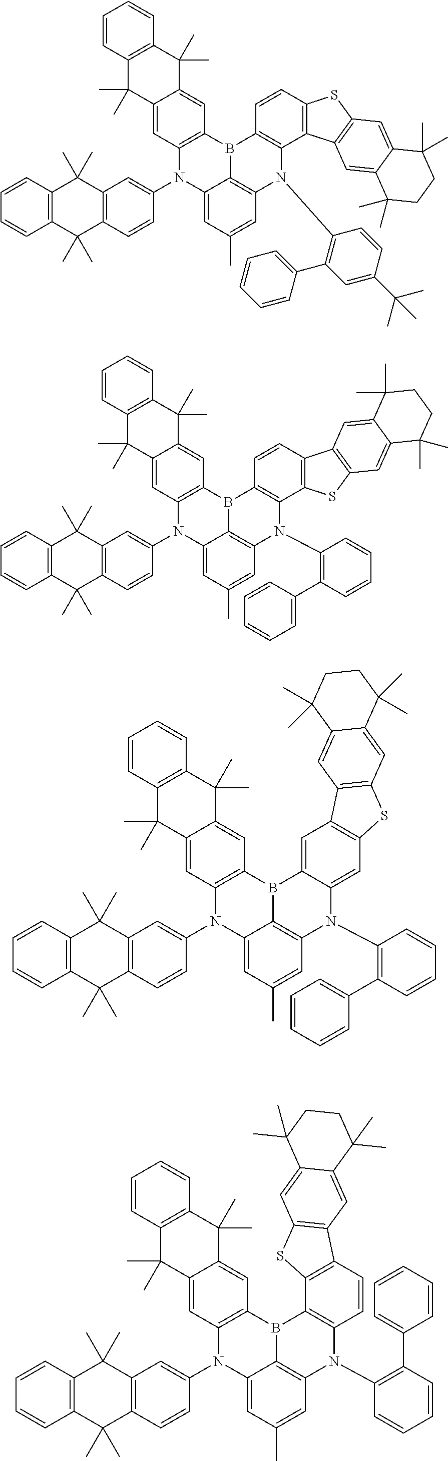

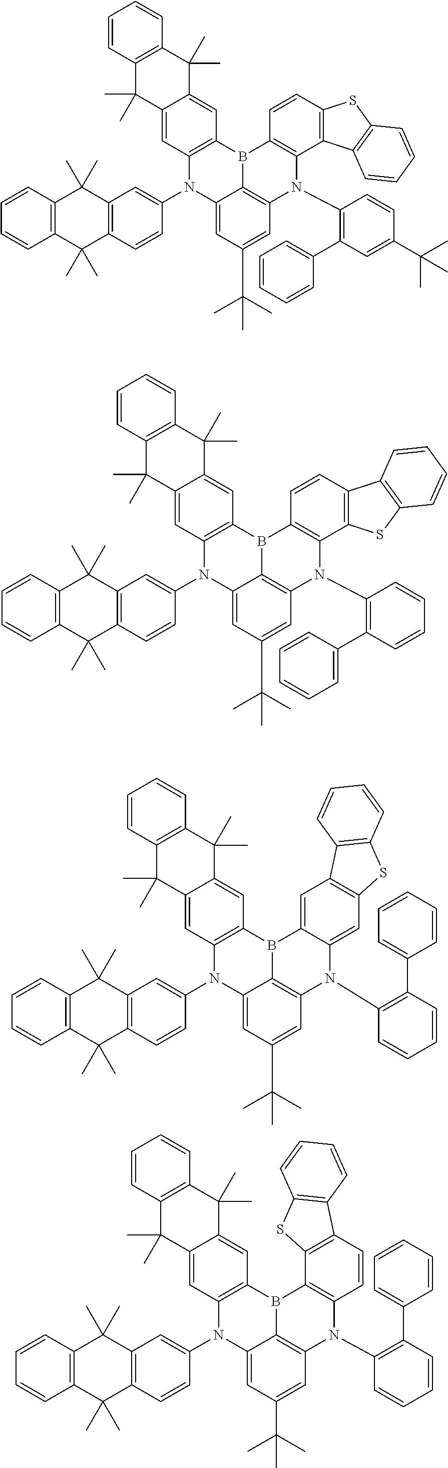

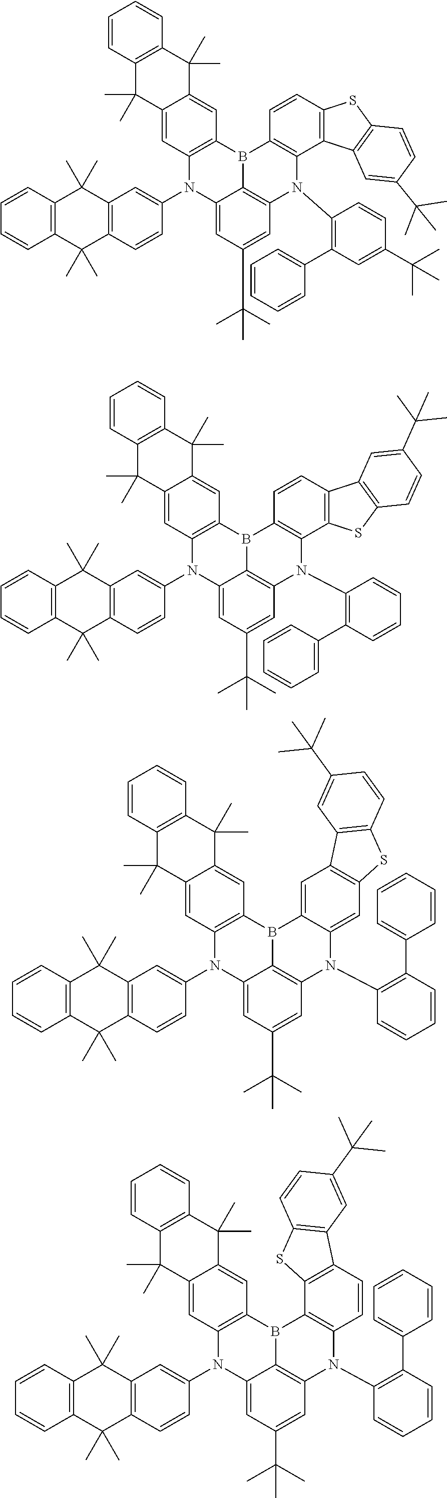

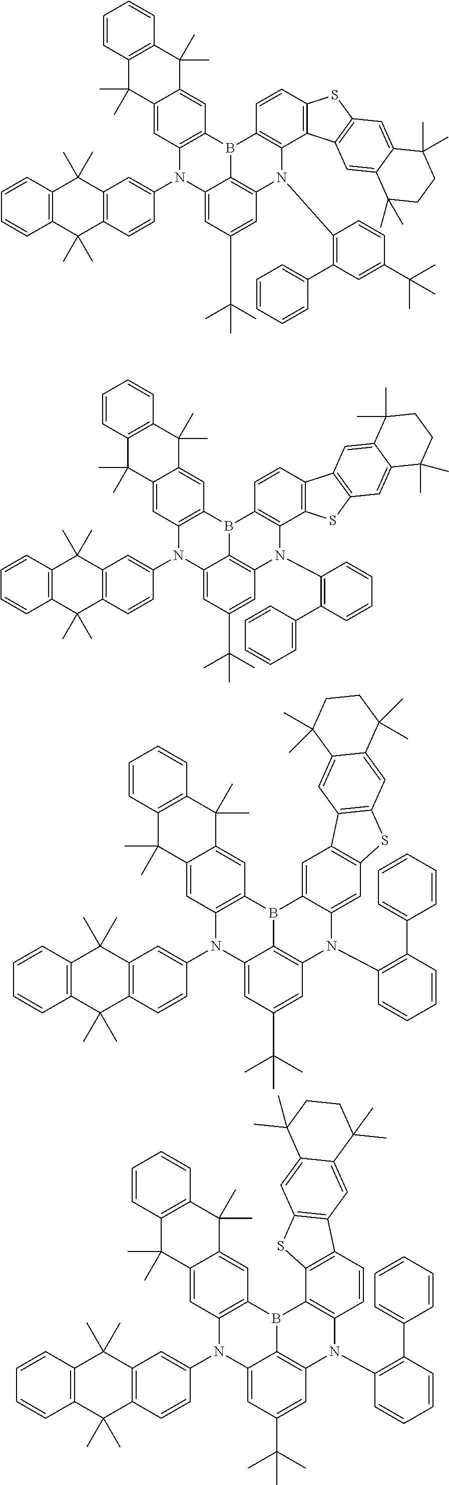

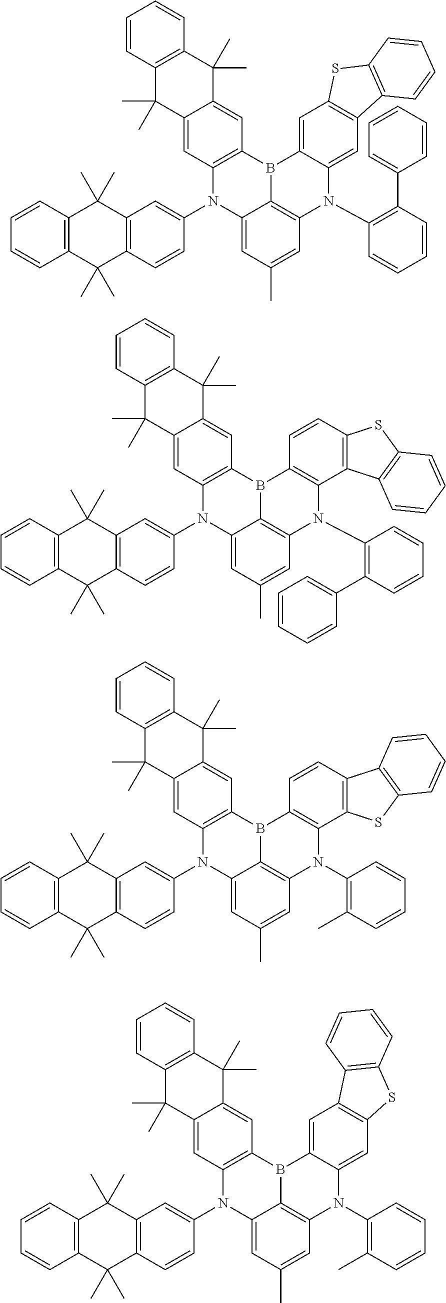

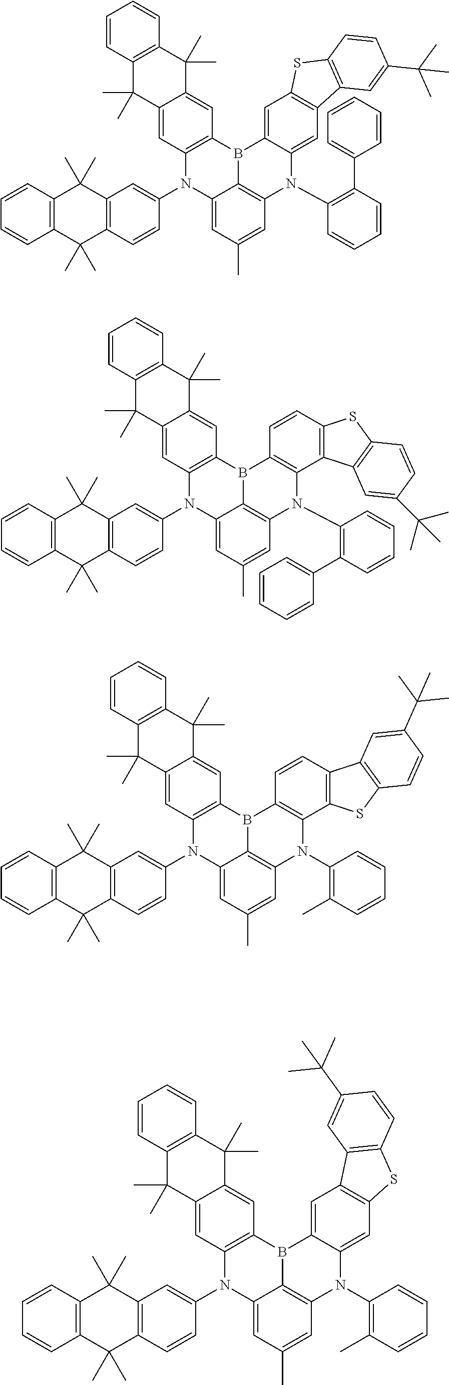

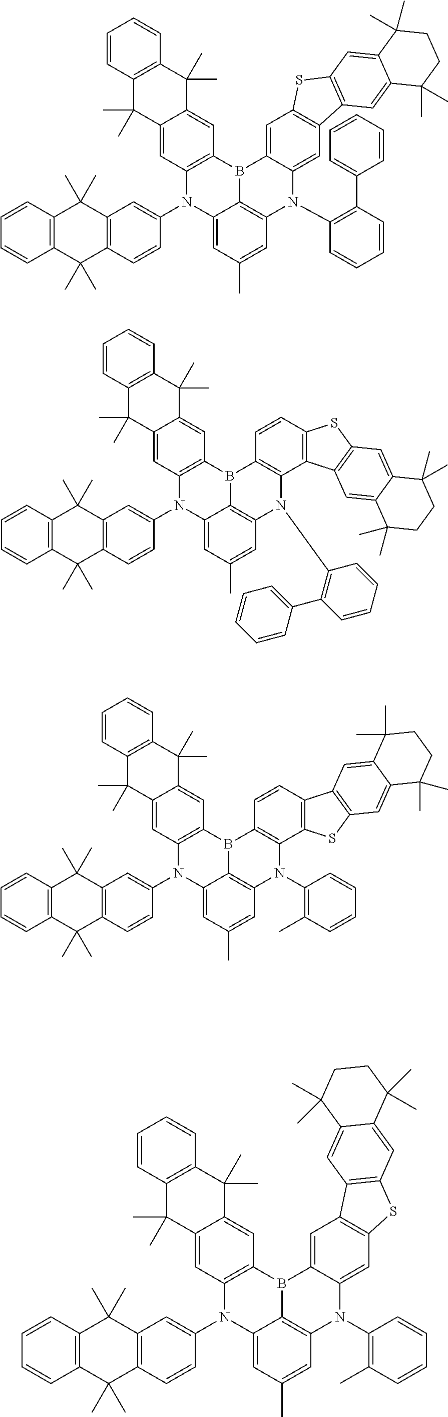

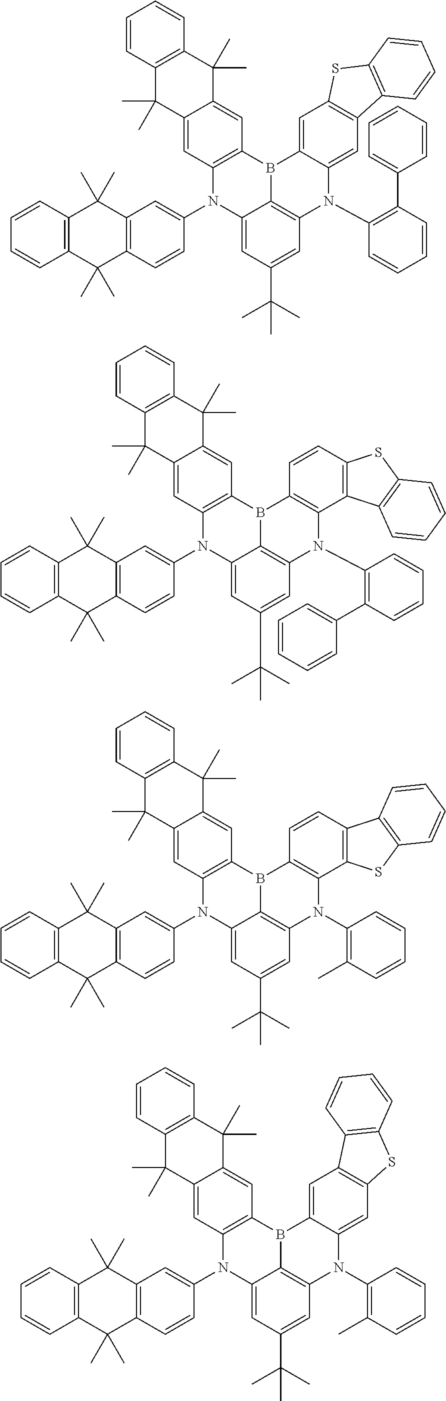

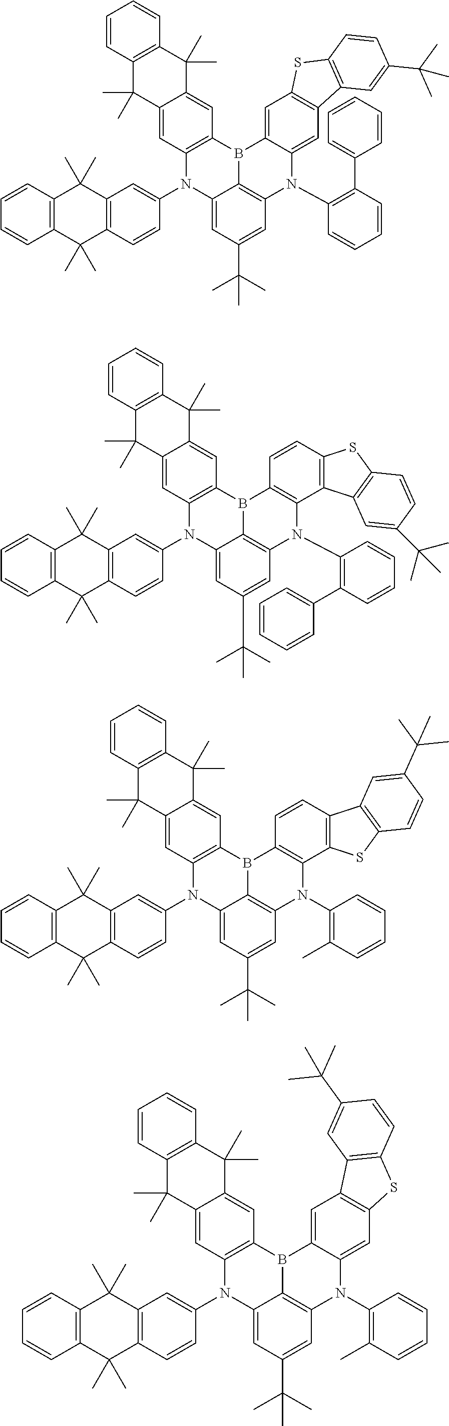

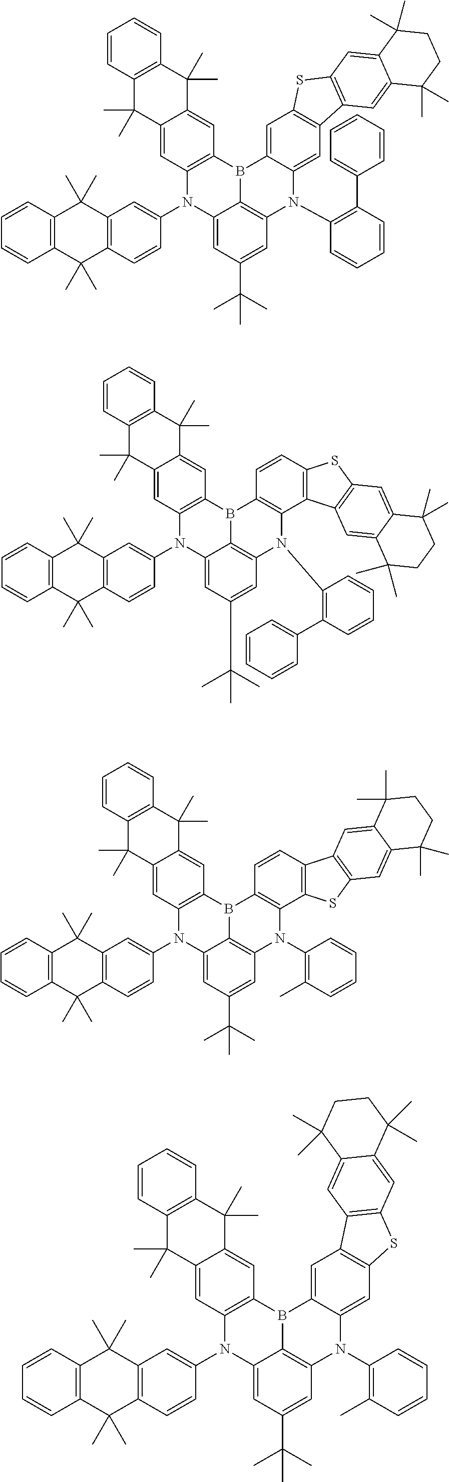

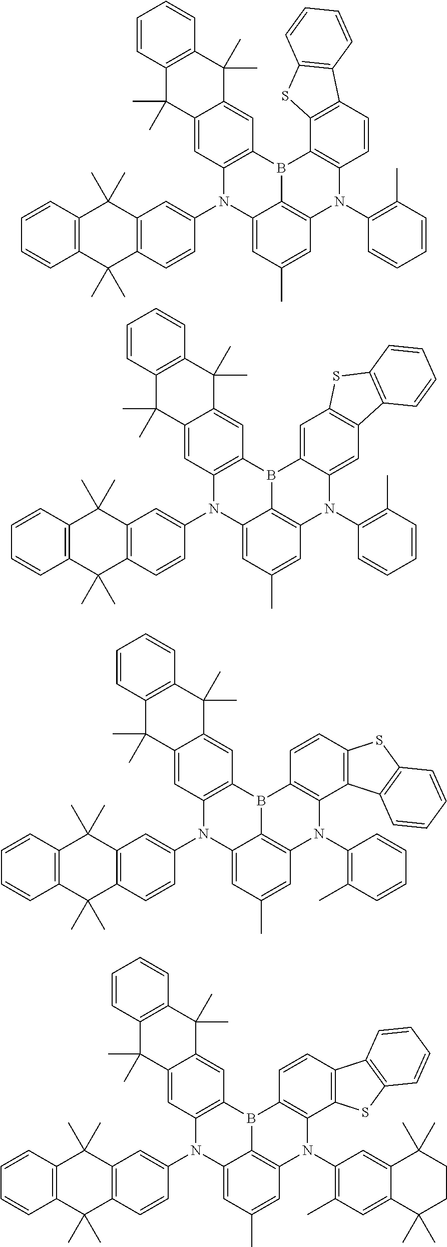

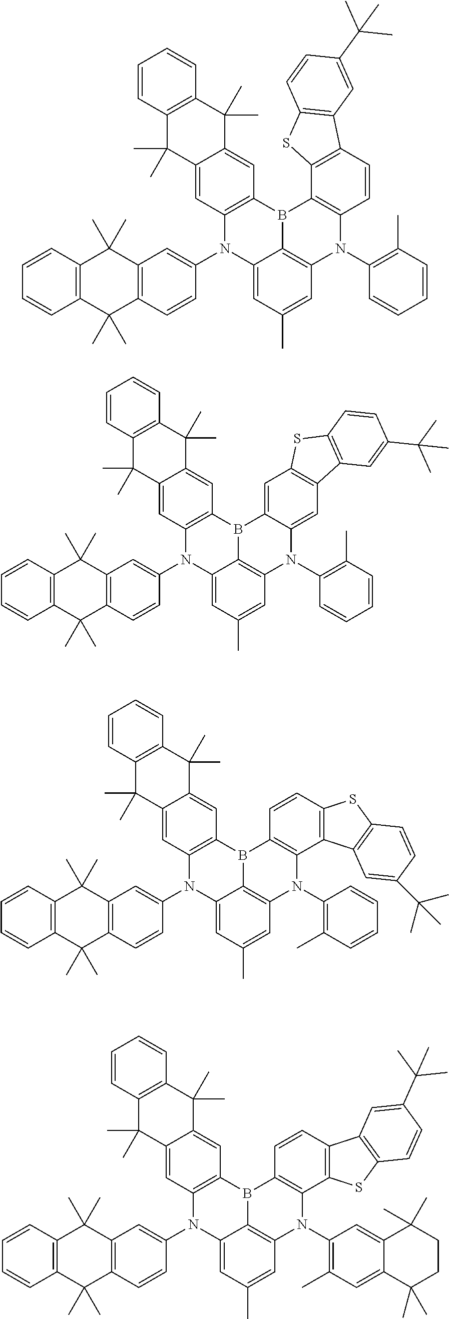

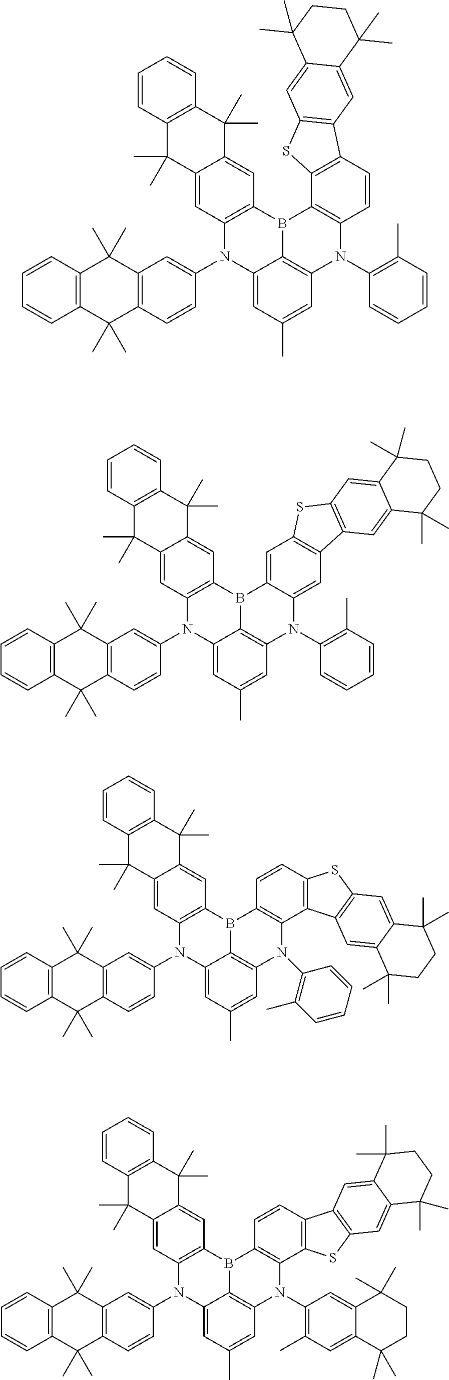

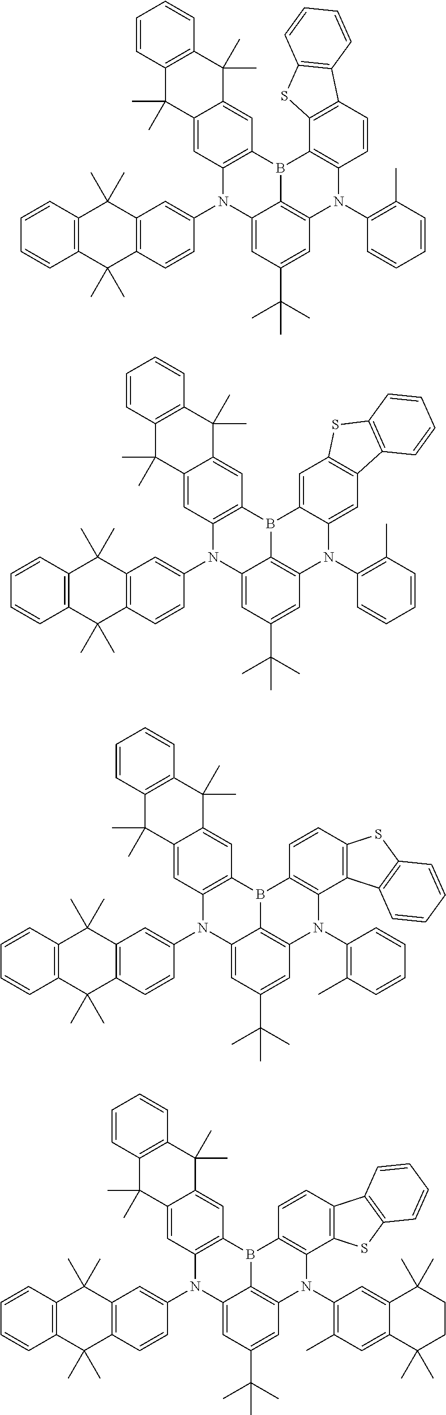

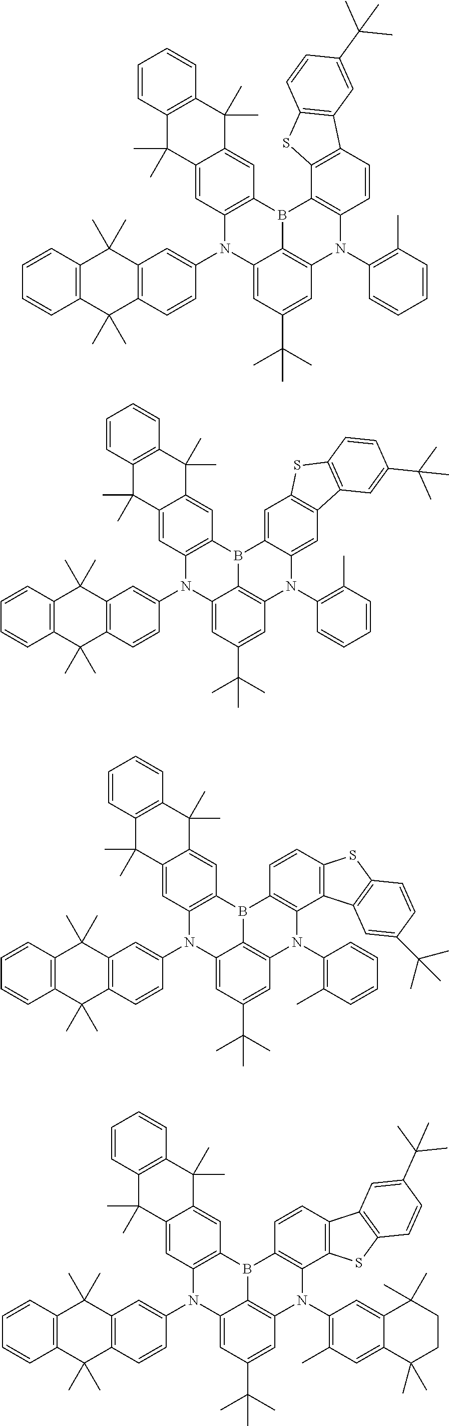

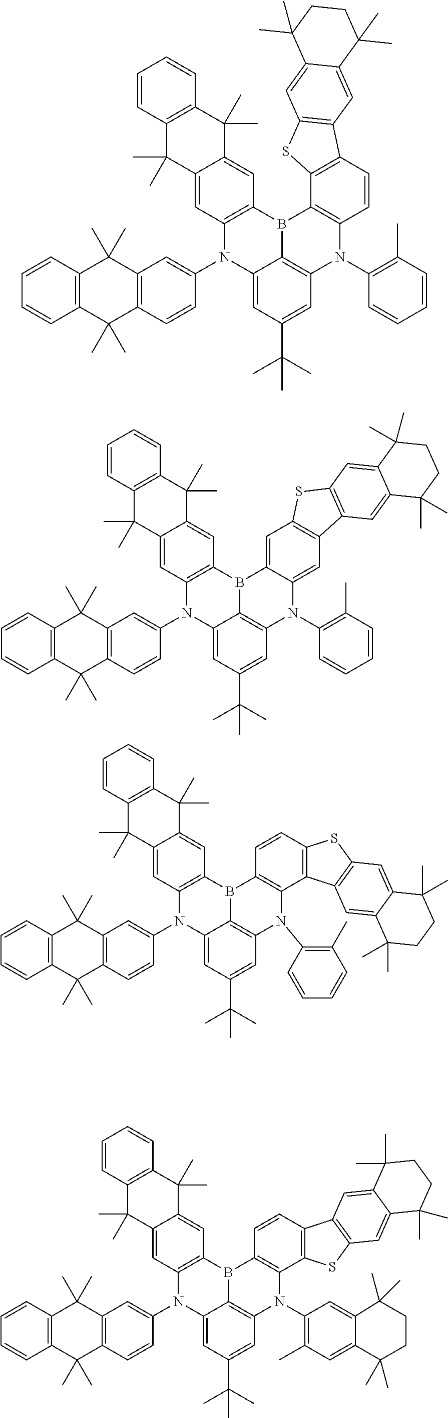

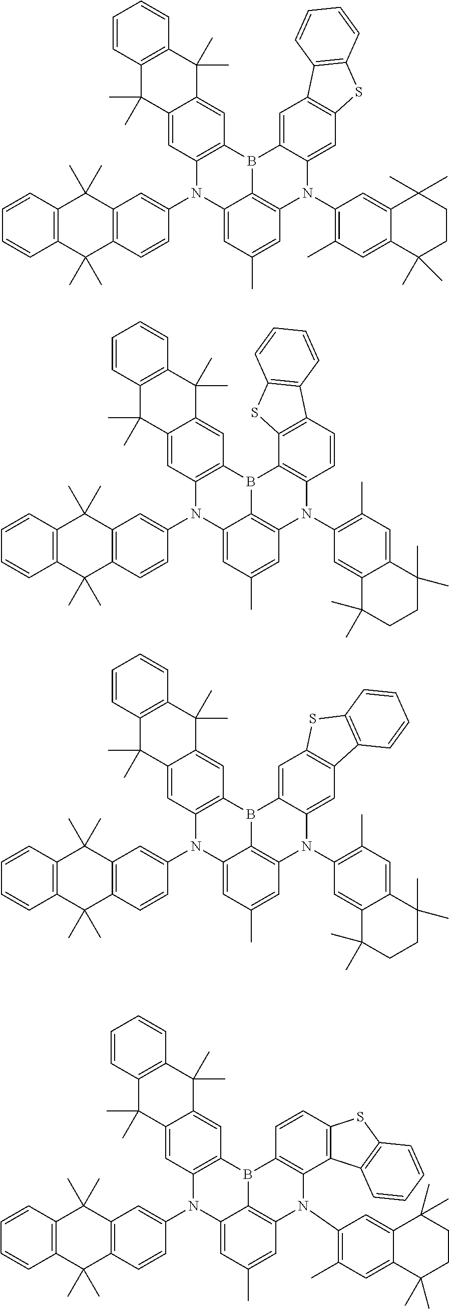

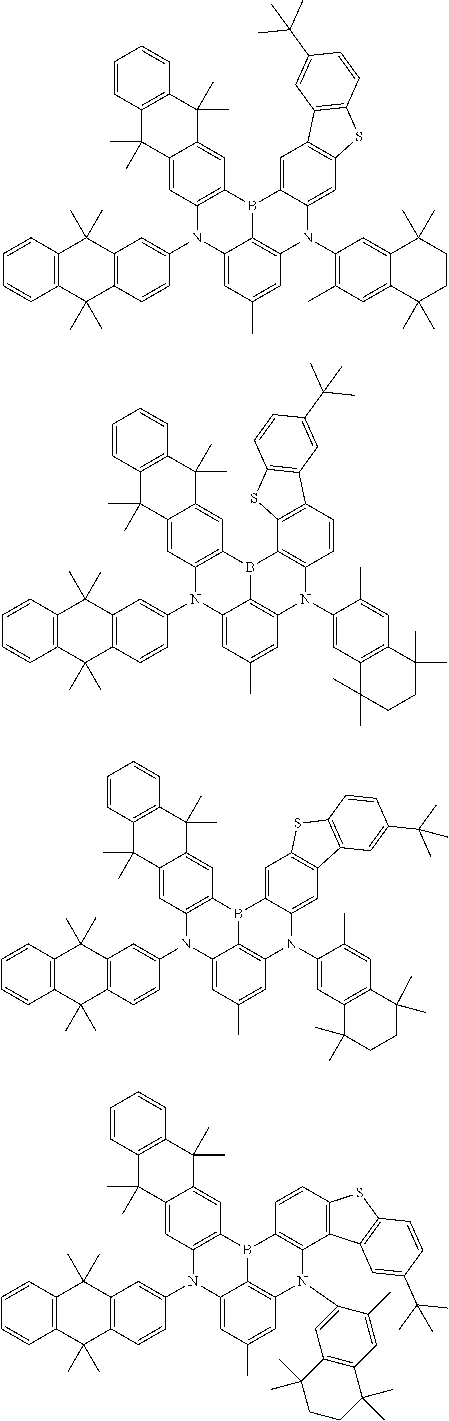

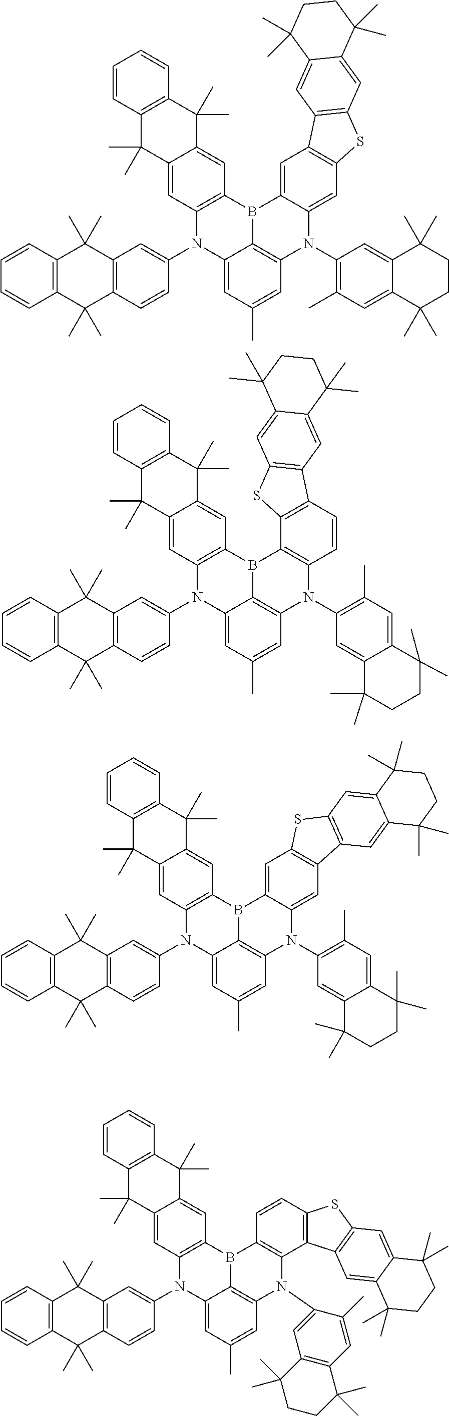

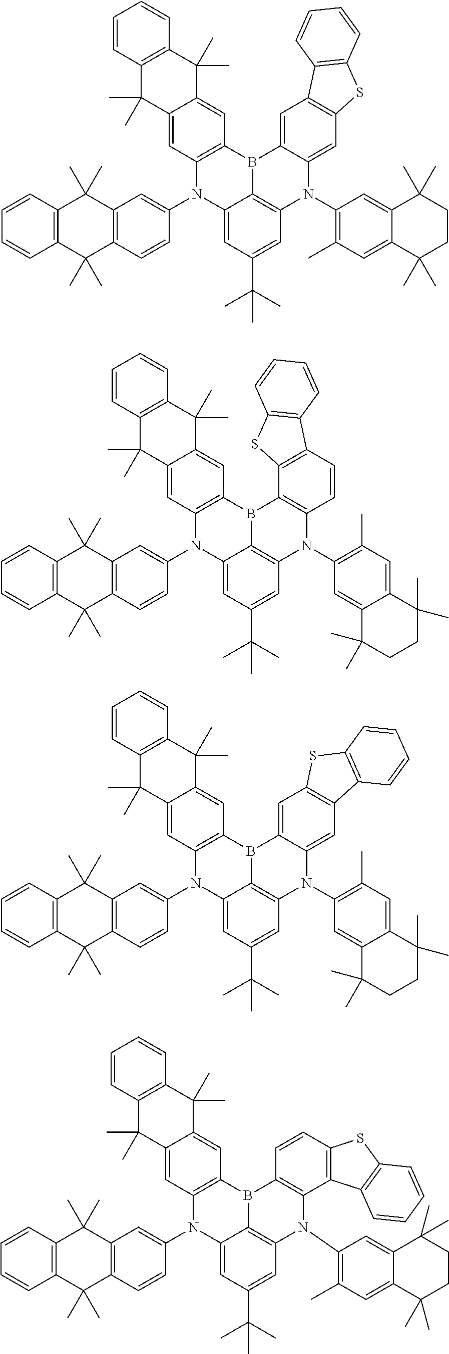

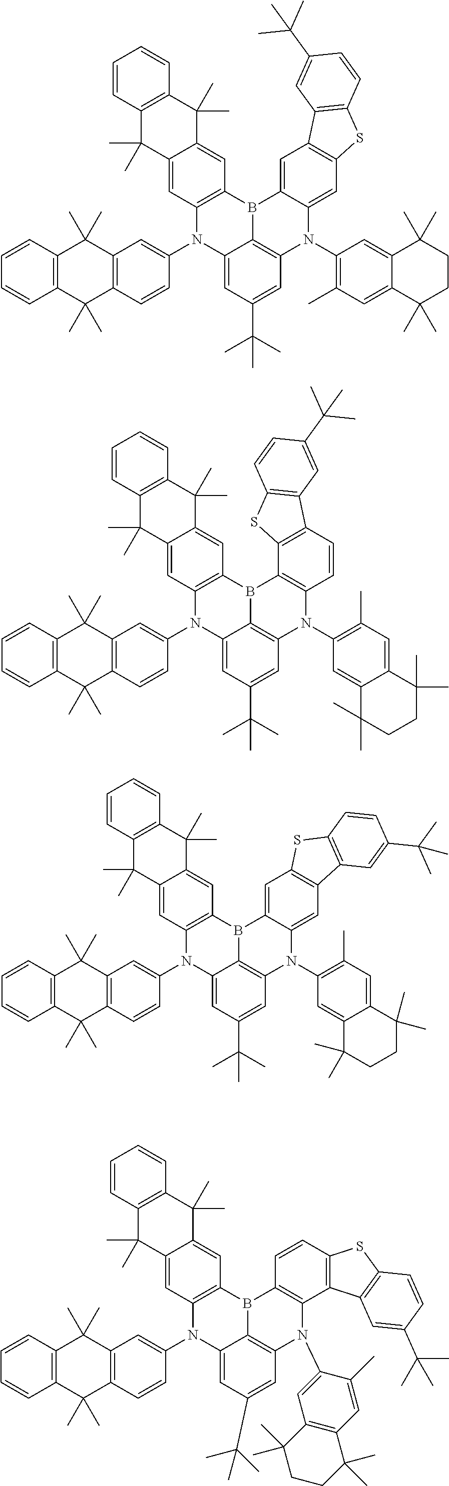

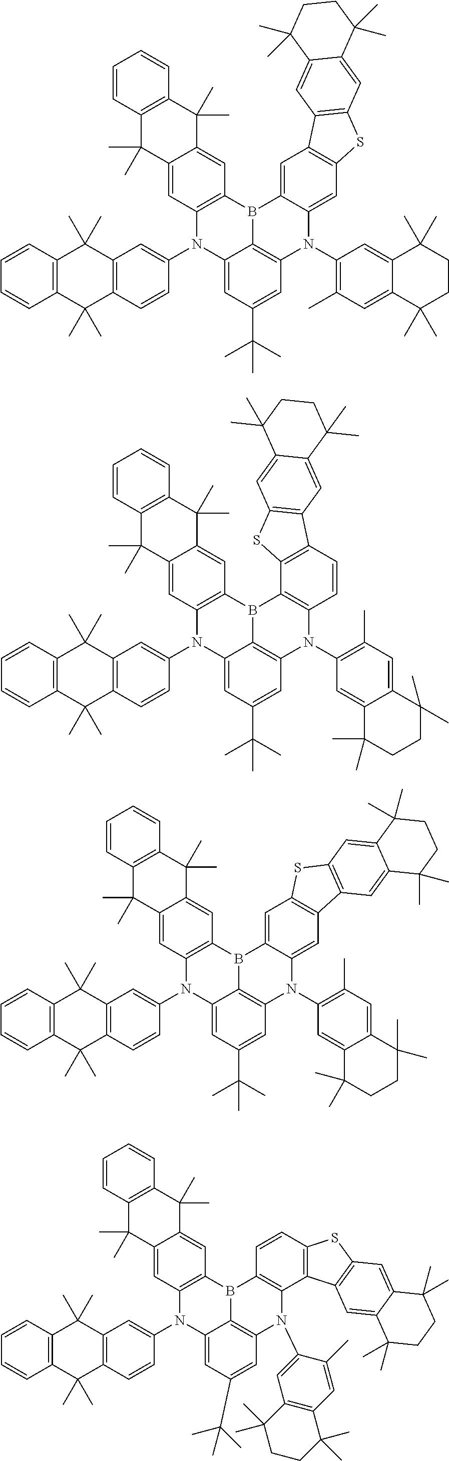

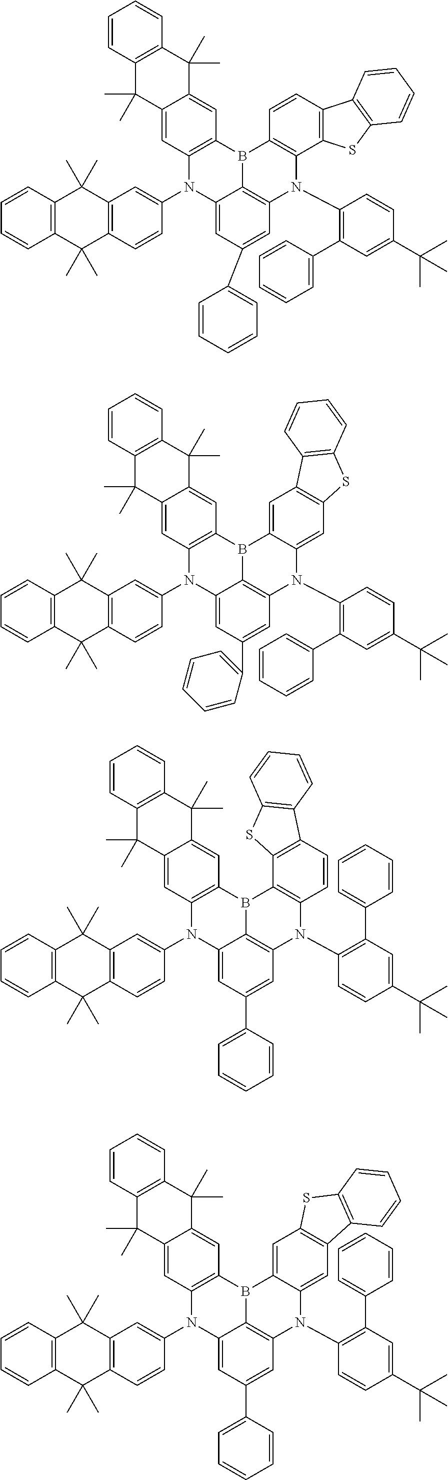

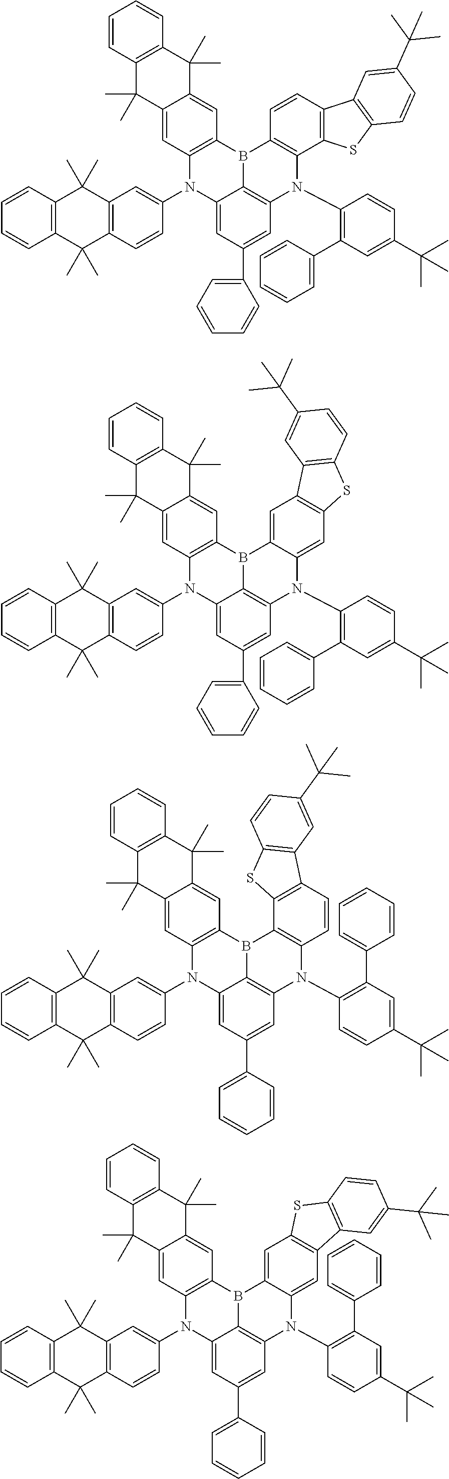

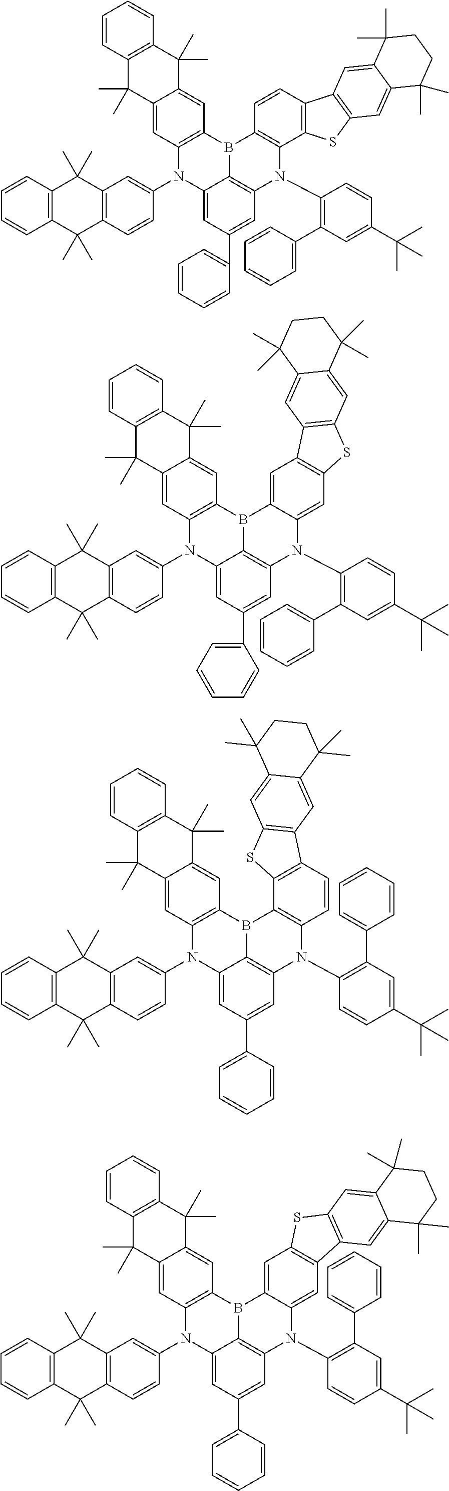

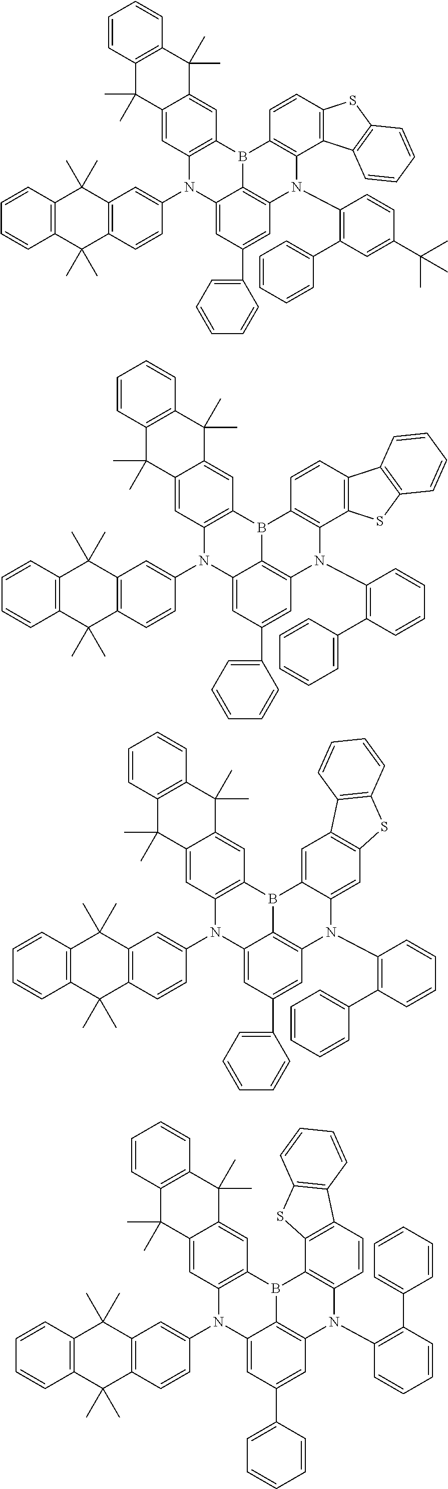

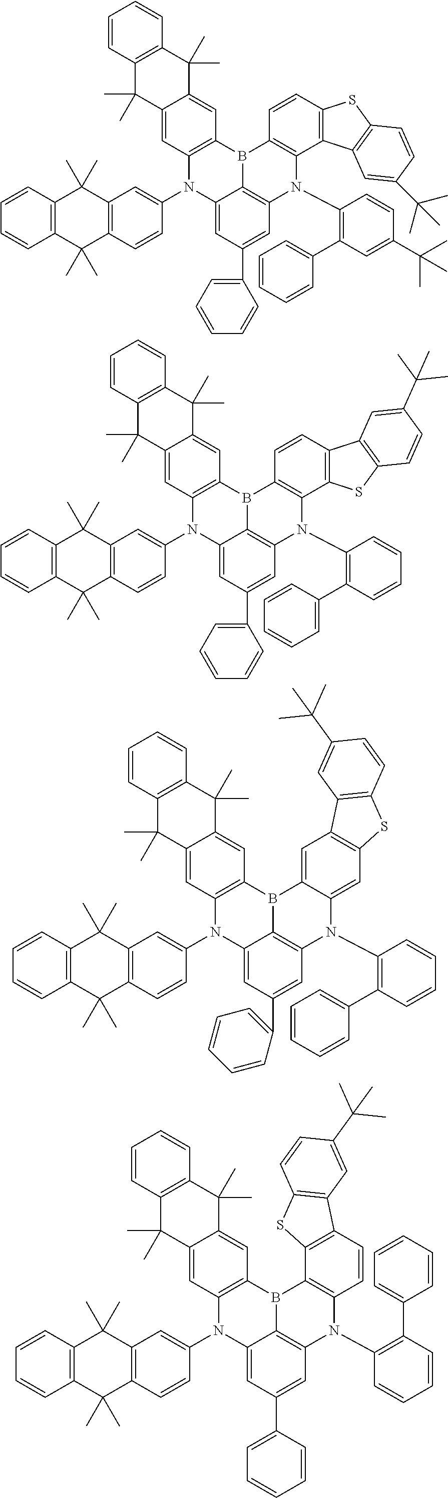

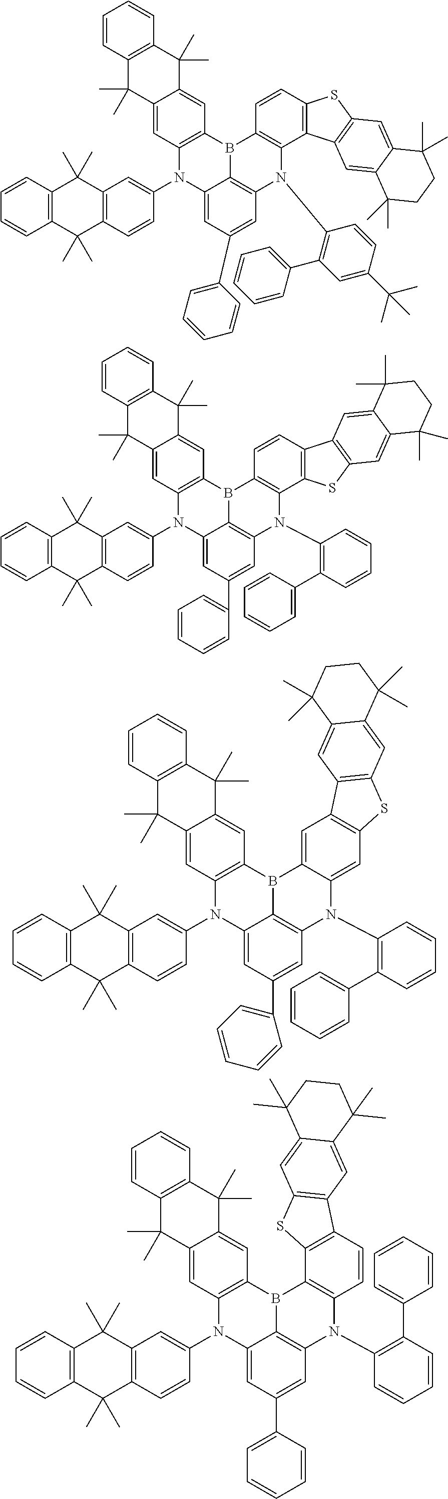

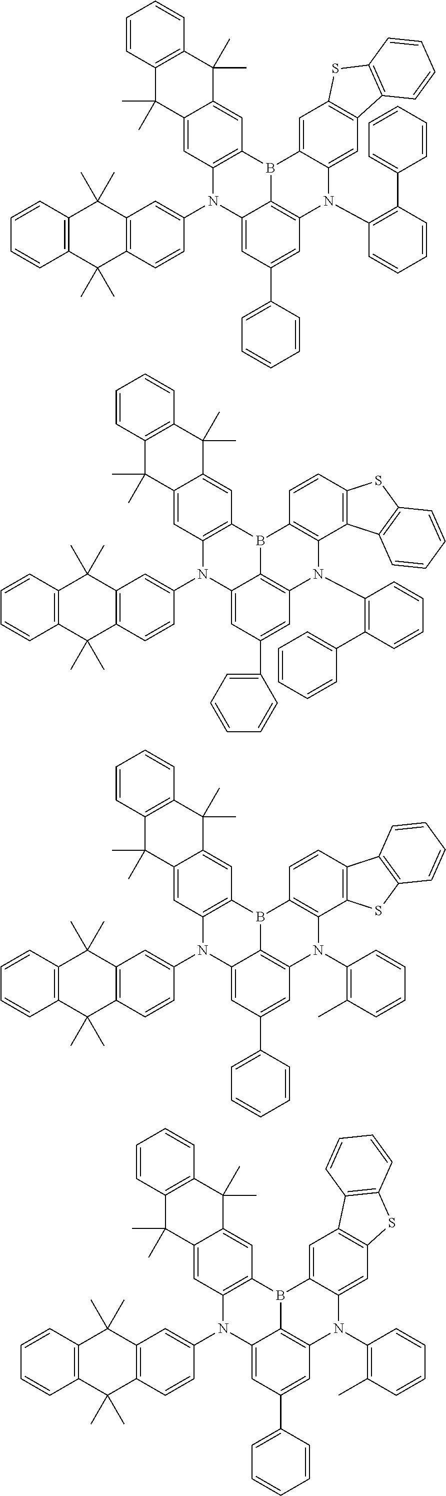

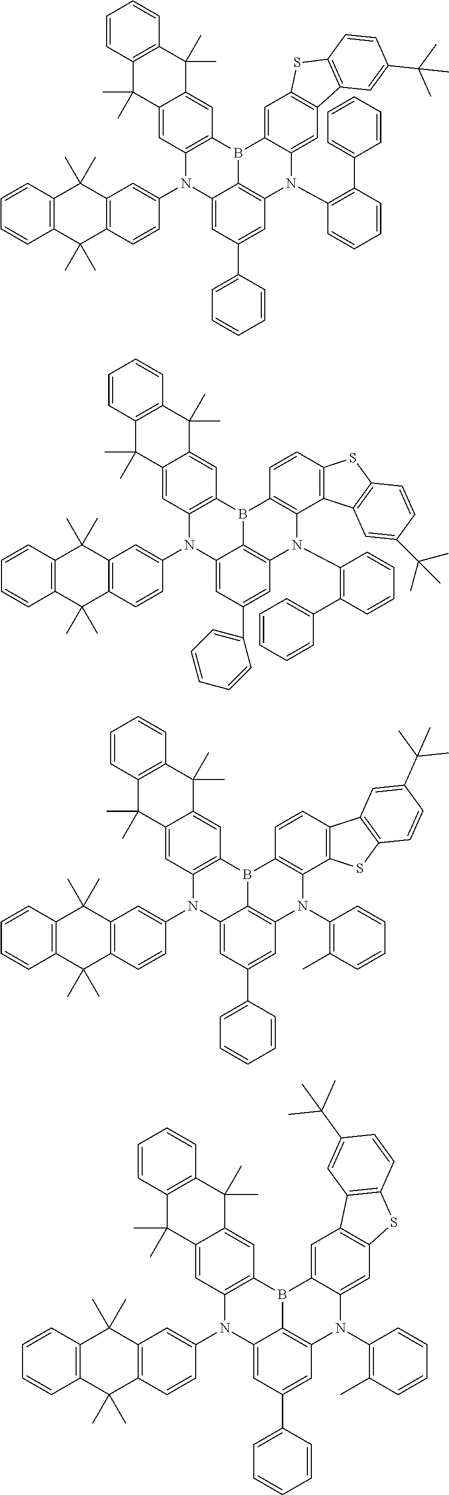

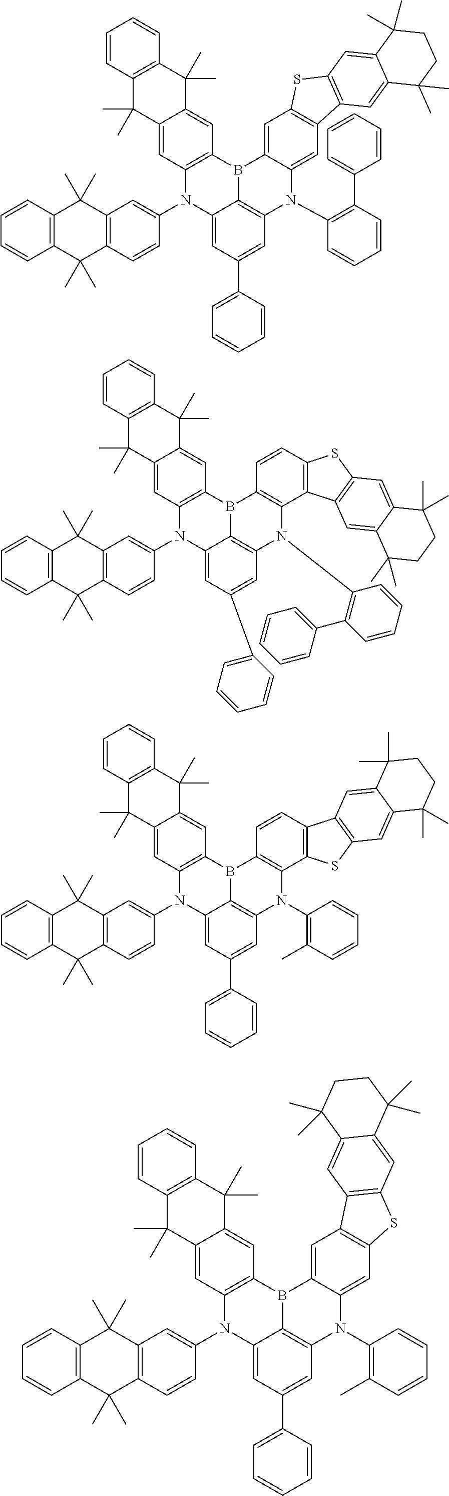

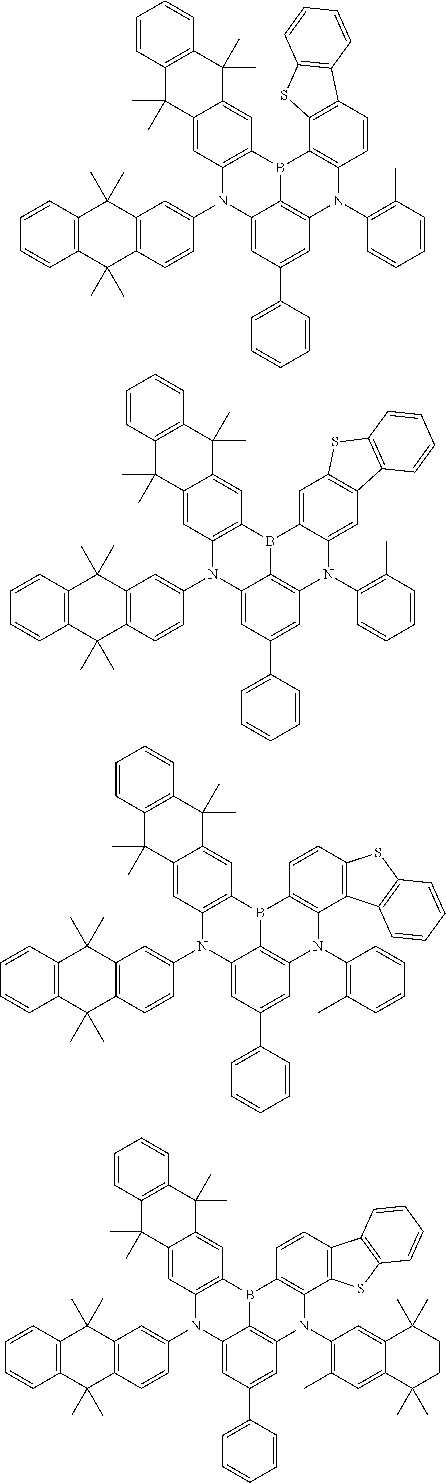

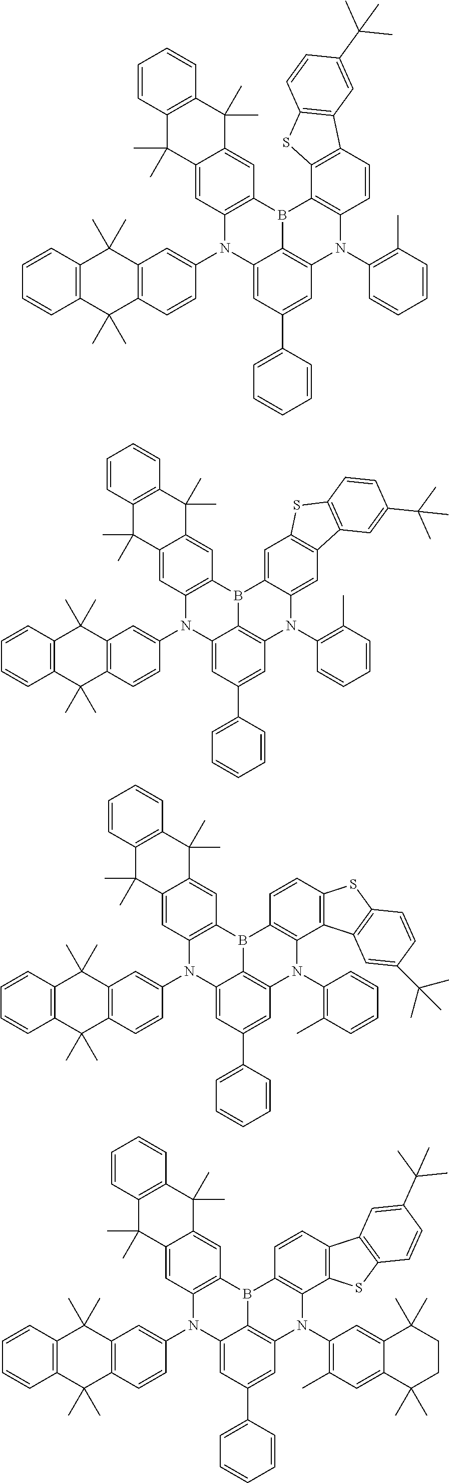

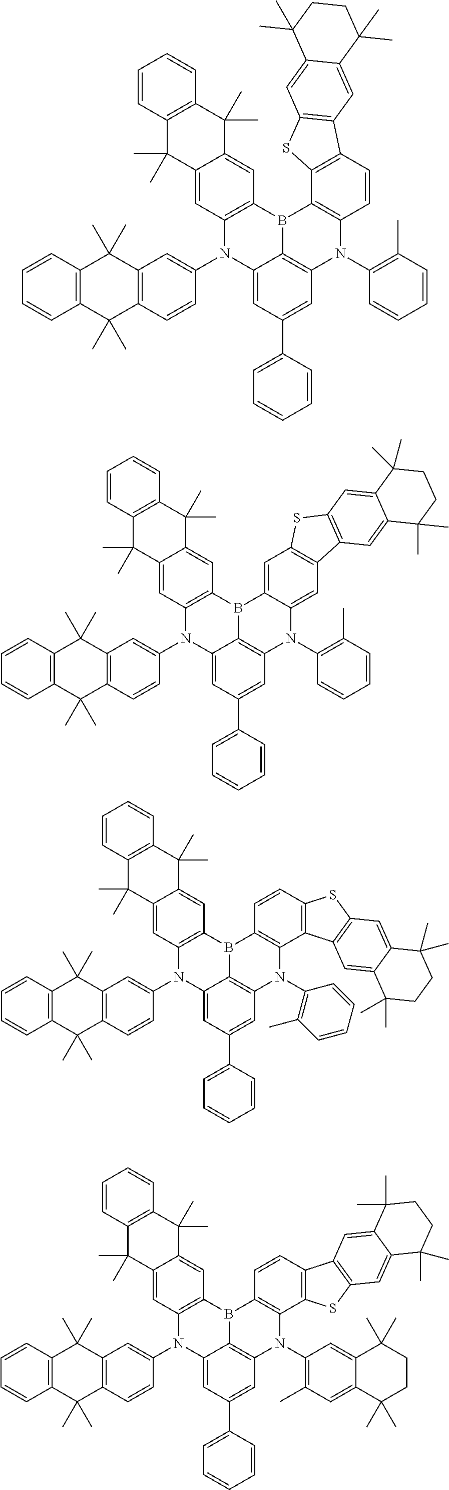

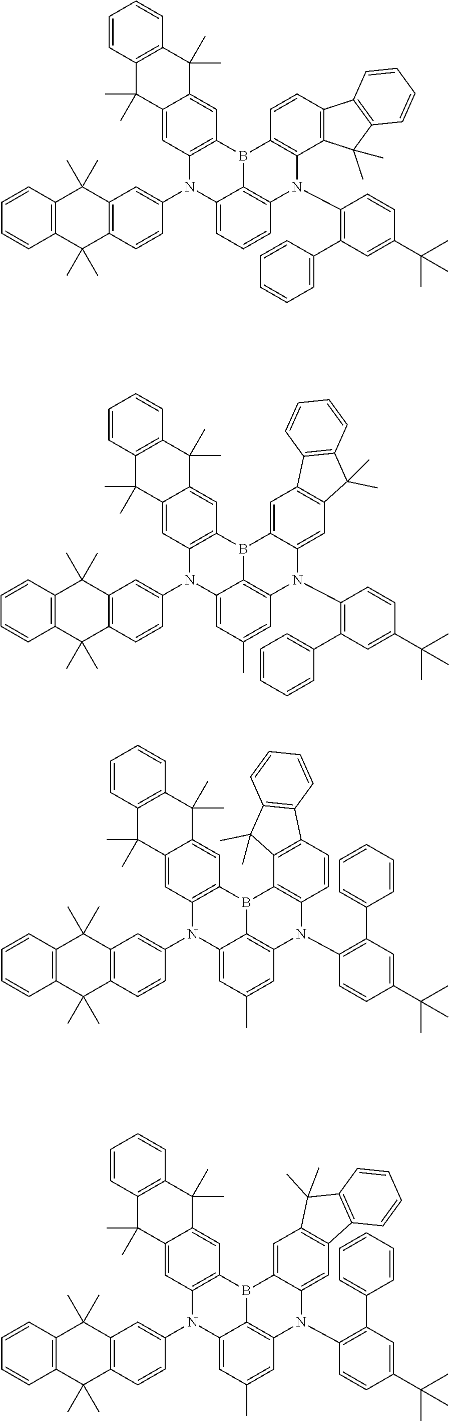

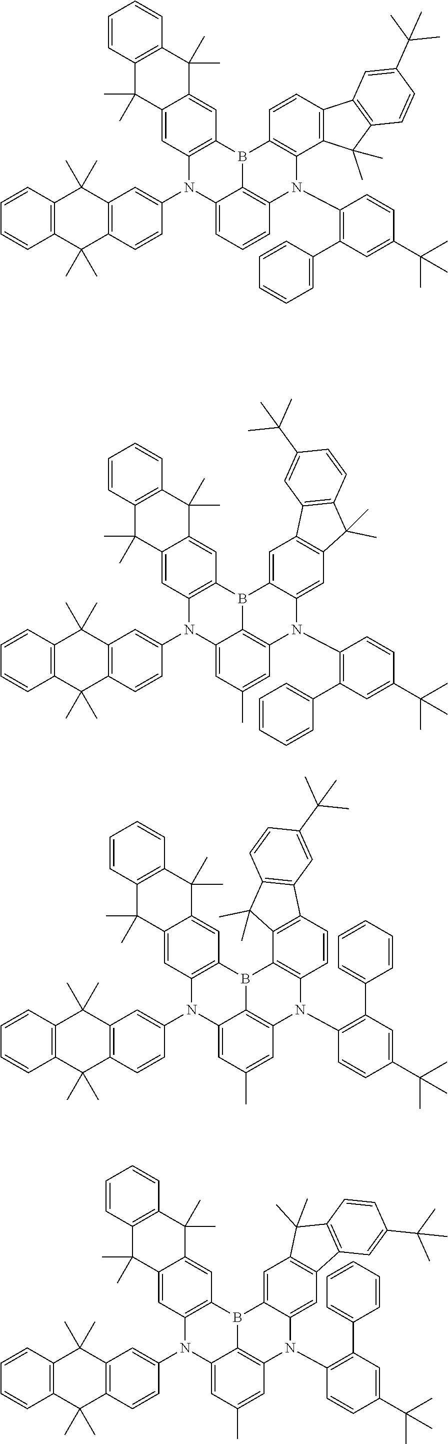

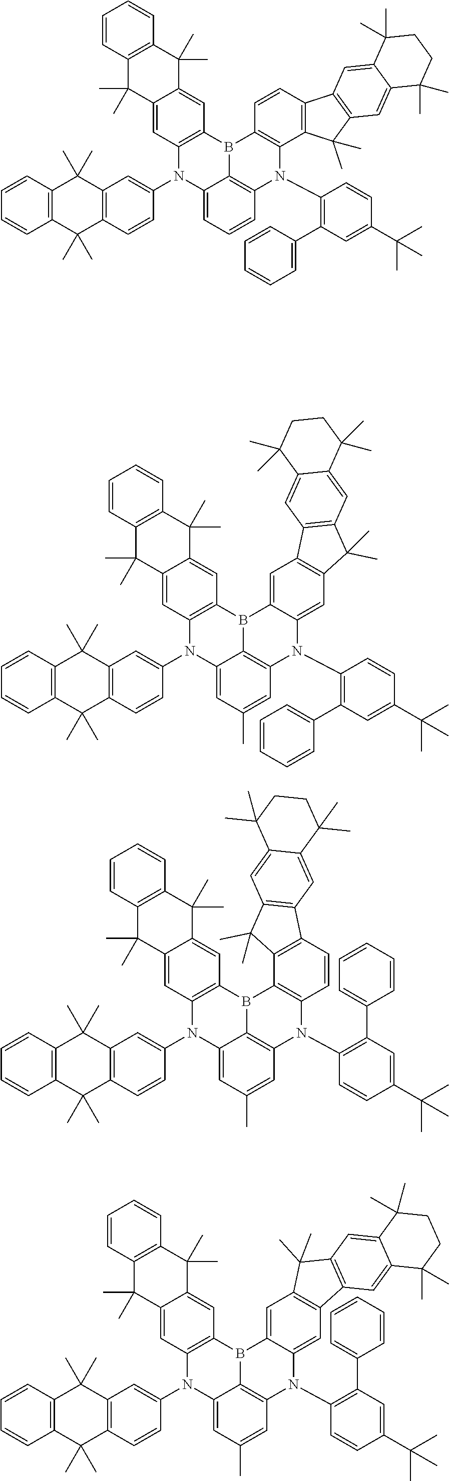

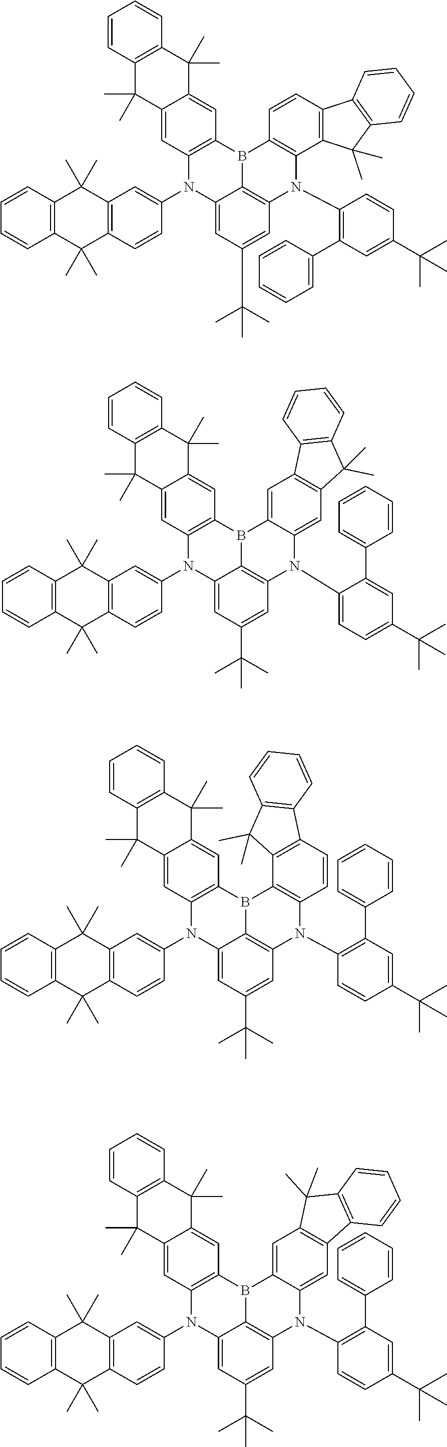

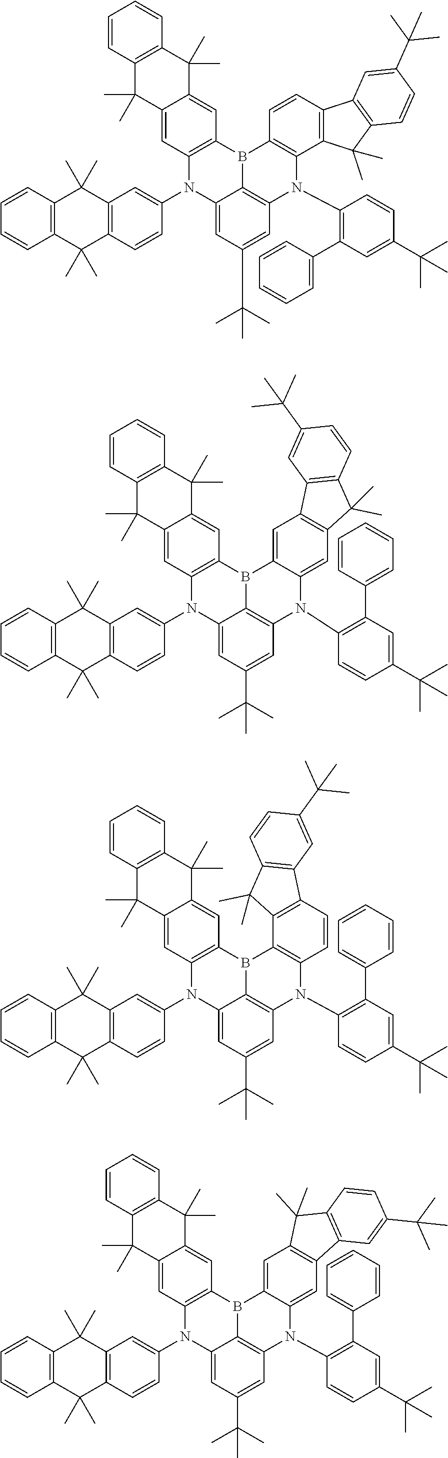

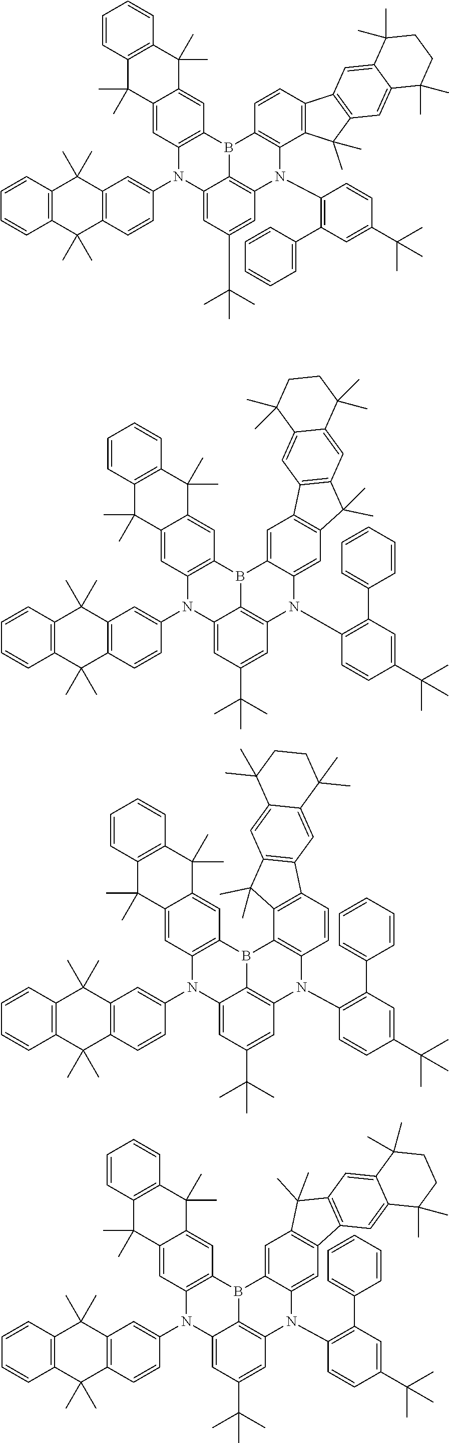

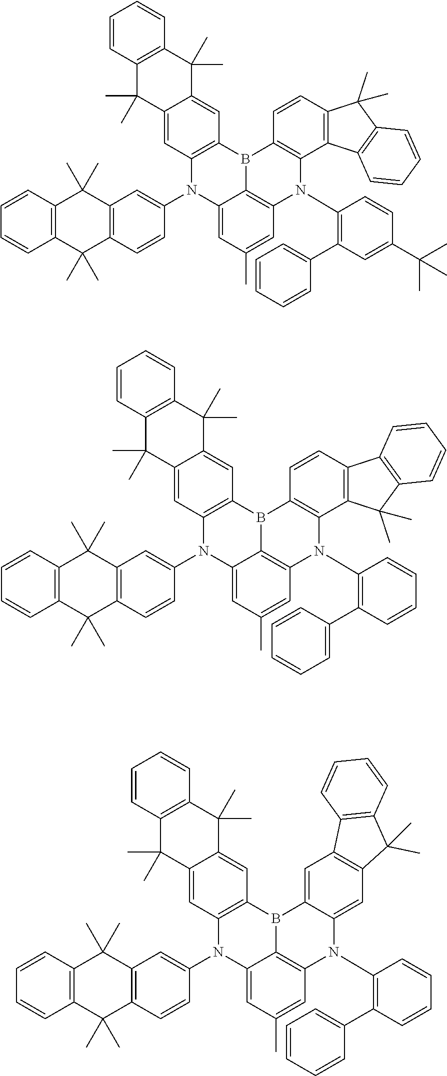 [SMILES: Cc1cc2c3c(c1)N(c1ccc(C(C)(C)C)cc1-c1ccccc1)c1c(ccc4c1-c1ccccc1C4(C)C)B3c1cc3c(cc1N2c1ccc2c(c1)C(C)(C)c1ccccc1C2(C)C)C(C)(C)c1ccccc1C3(C)C ; Cc1cc2c3c(c1)N(c1ccccc1-c1ccccc1)c1c(ccc4c1C(C)(C)c1ccccc1-4)B3c1cc3c(cc1N2c1ccc2c(c1)C(C)(C)c1ccccc1C2(C)C)C(C)(C)c1ccccc1C3(C)C ; Cc1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)-c1ccccc1C4(C)C]

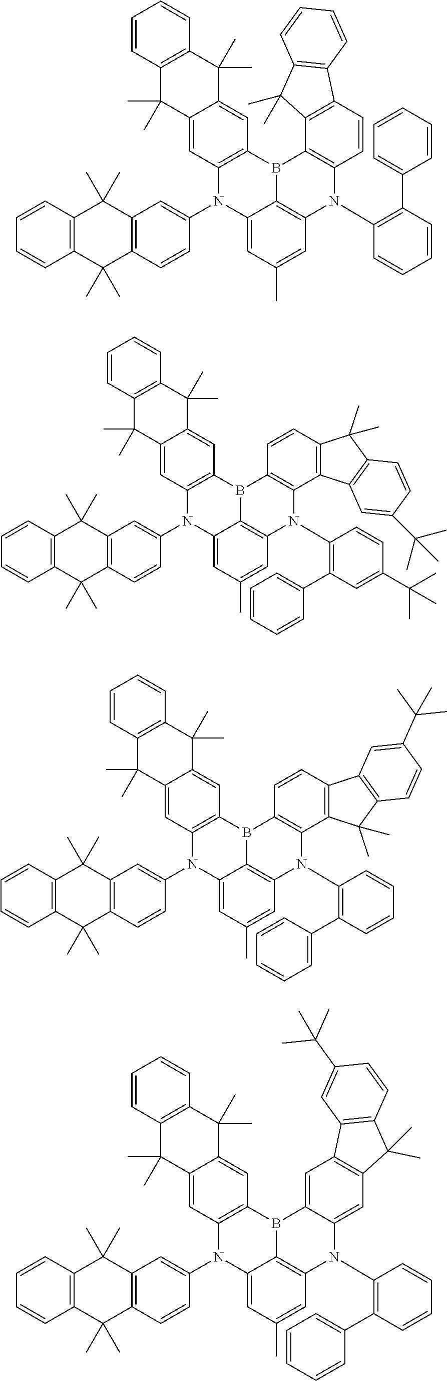

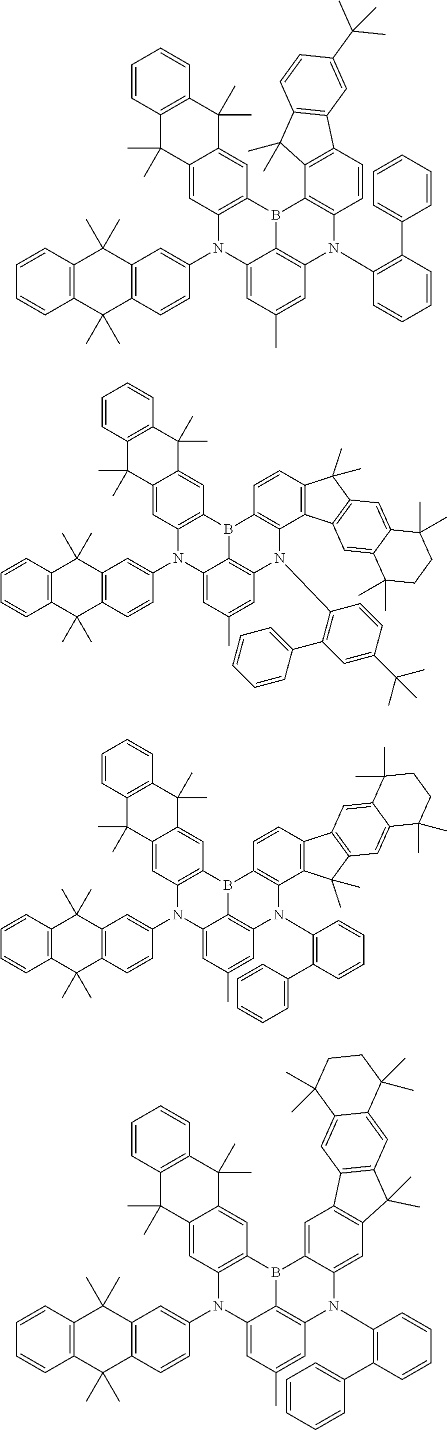

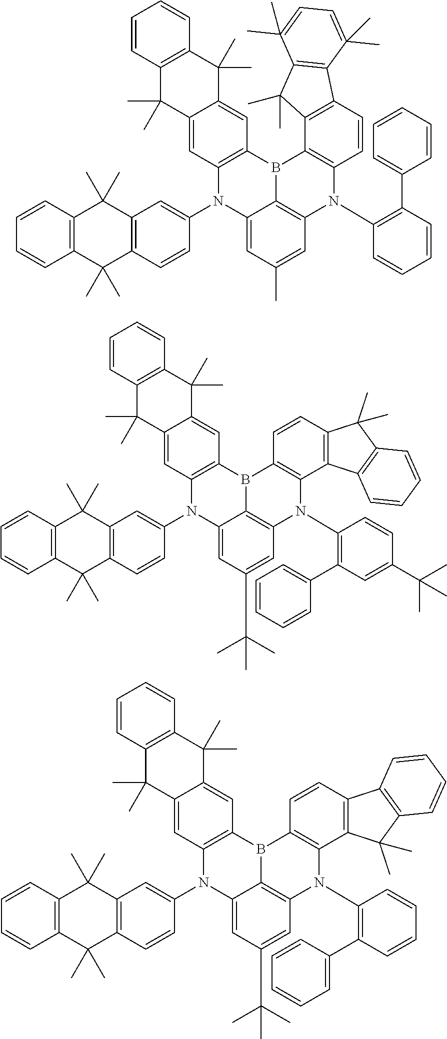

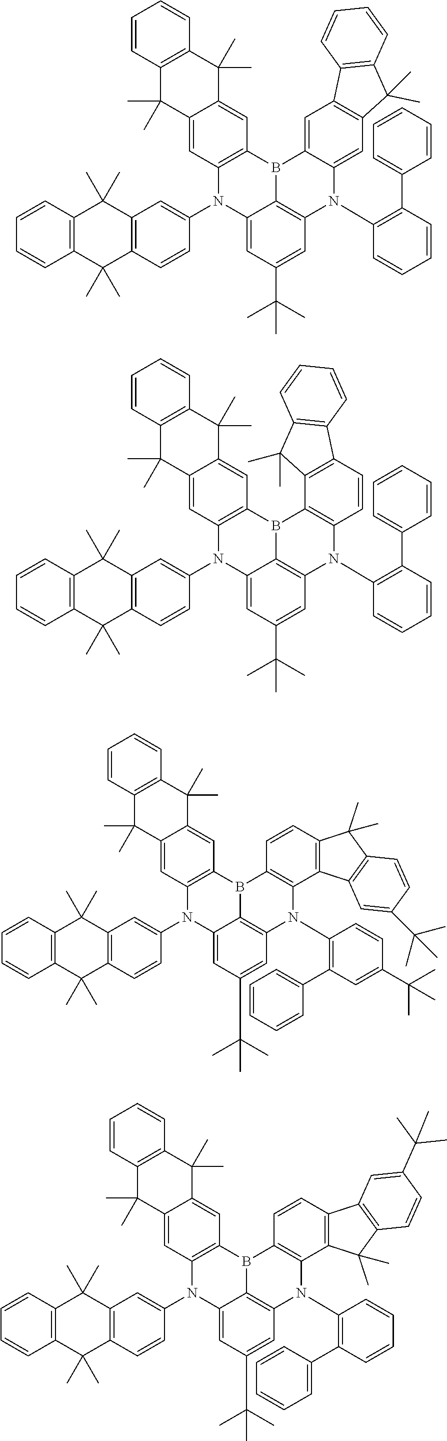

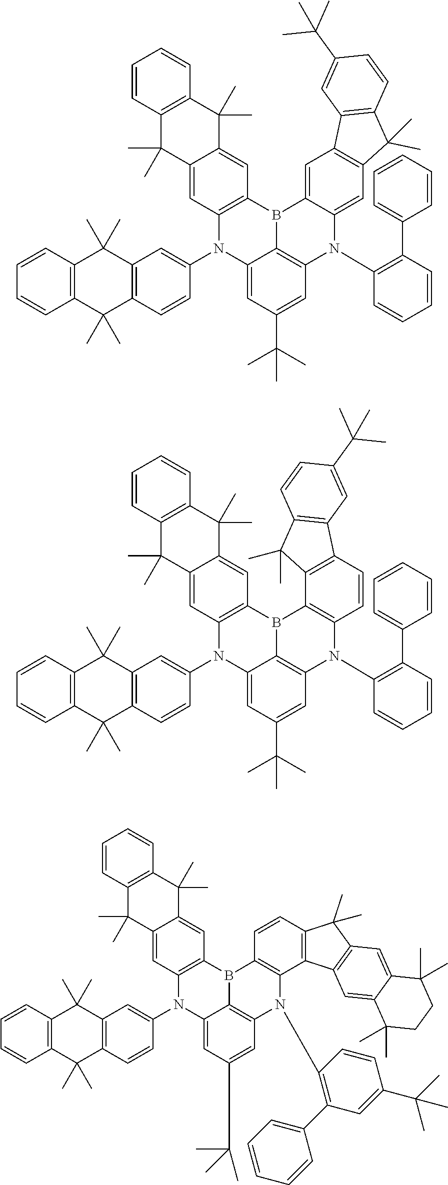 [SMILES: CC(C)(C)c1ccc2c(c1)-c1cc3c(cc1C2(C)C)N(c1ccccc1-c1ccccc1)c1cc(C(C)(C)C)cc2c1B3c1cc3c(cc1N2c1ccc2c(c1)C(C)(C)c1ccccc1C2(C)C)C(C)(C)c1ccccc1C3(C)C ; CC(C)(C)c1ccc2c(c1)-c1ccc3c(c1C2(C)C)B1c2cc4c(cc2N(c2ccc5c(c2)C(C)(C)c2ccccc2C5(C)C)c2cc(C(C)(C)C)cc(c21)N3c1ccccc1-c1ccccc1)C(C)(C)c1ccccc1C4(C)C ; CC(C)(C)c1ccc(N2c3cc(C(C)(C)C)cc4c3B(c3cc5c(cc3N4c3ccc4c(c3)C(C)(C)c3ccccc3C4(C)C)C(C)(C)c3ccccc3C5(C)C)c3ccc4c(c32)-c2cc3c(cc2C4(C)C)C(C)(C)CCC3(C)C)c(-c2ccccc2)c1]

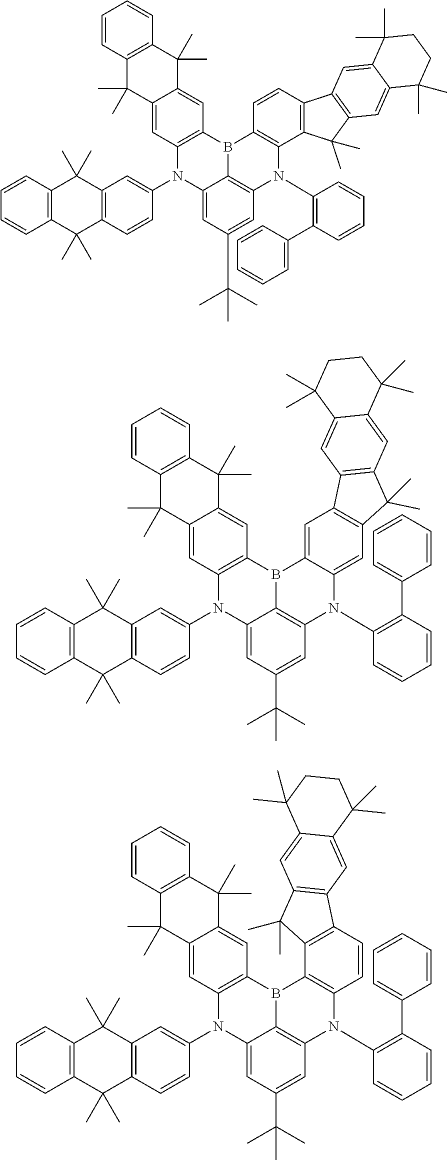

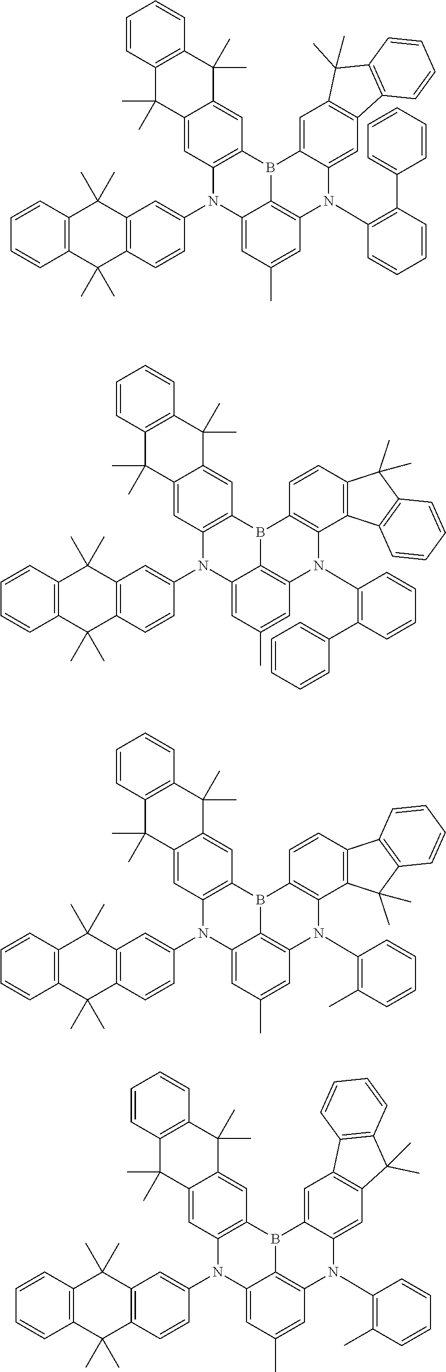

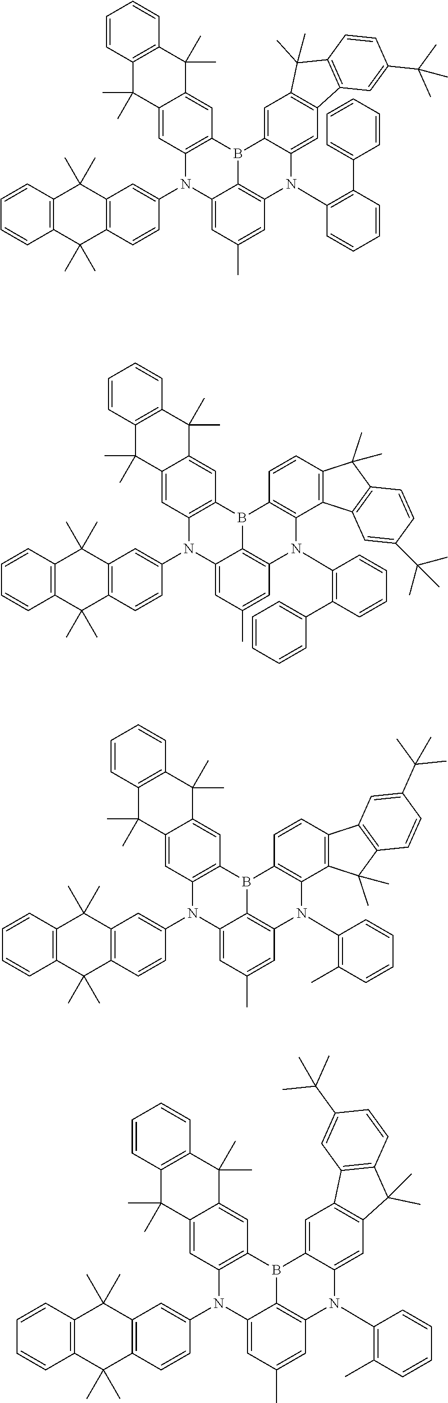

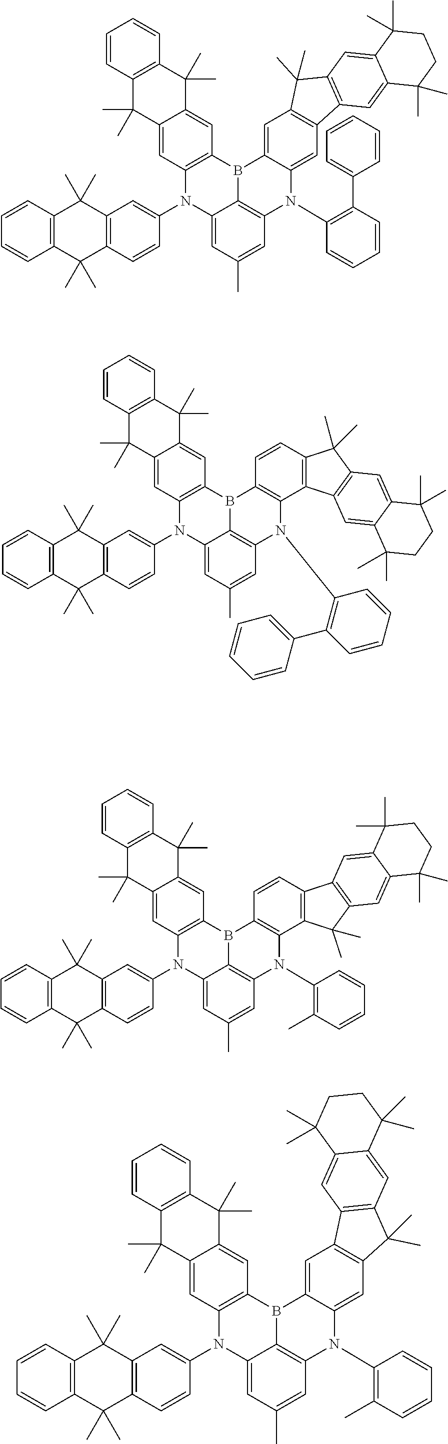

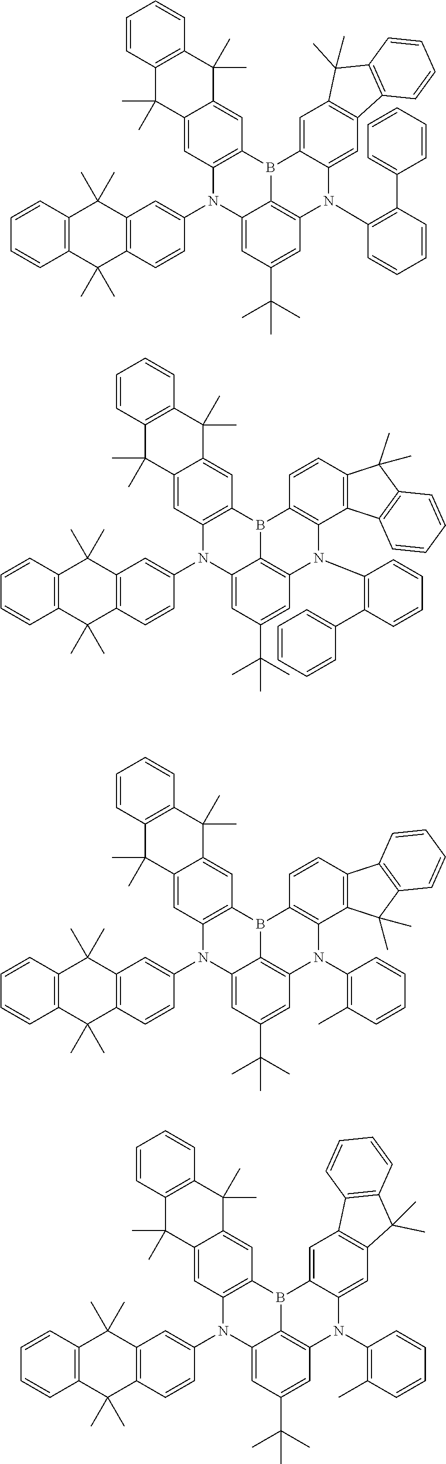

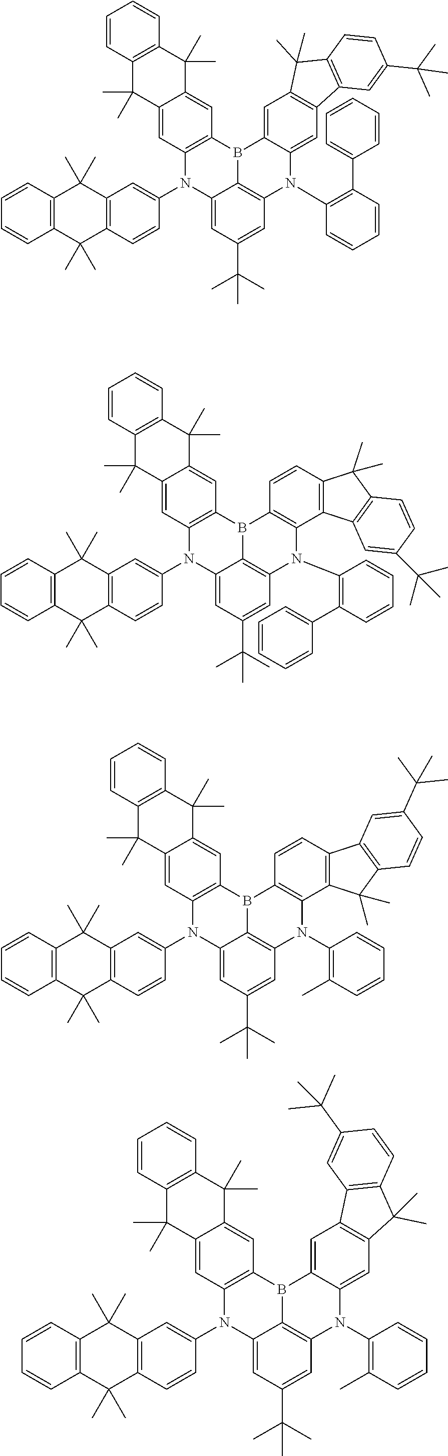

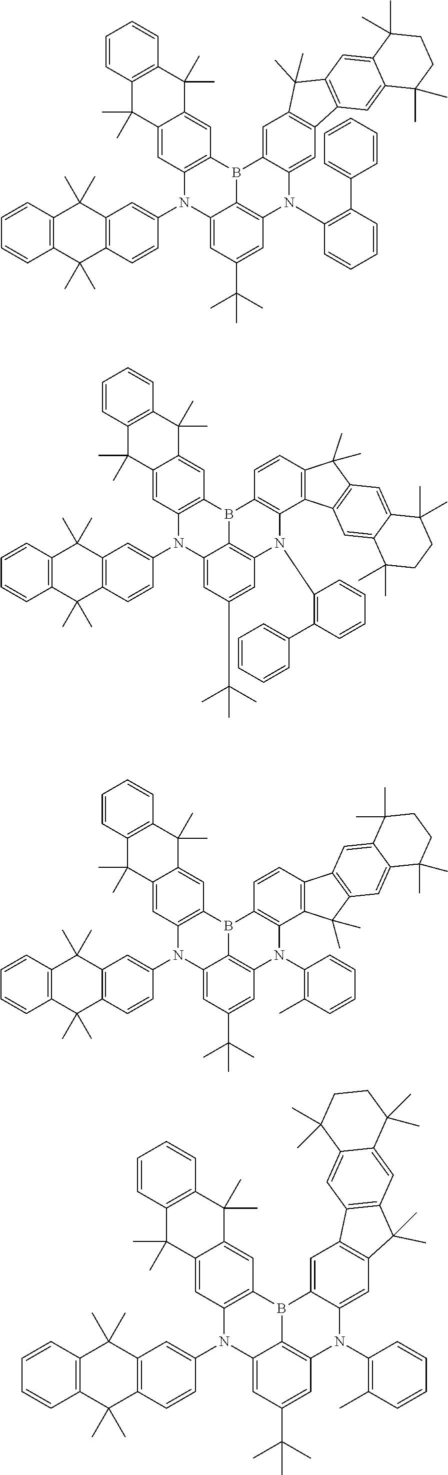

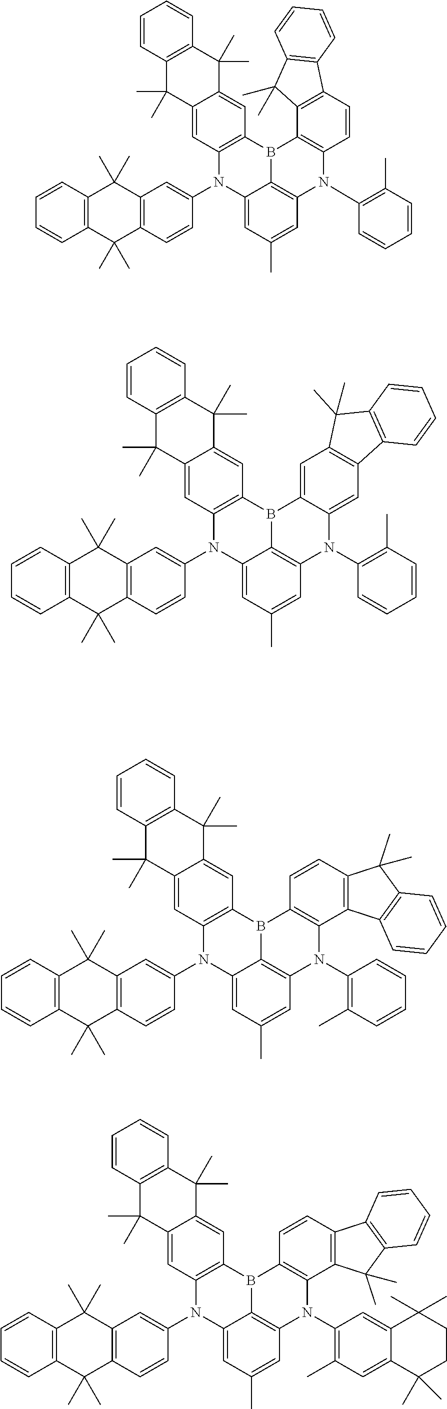

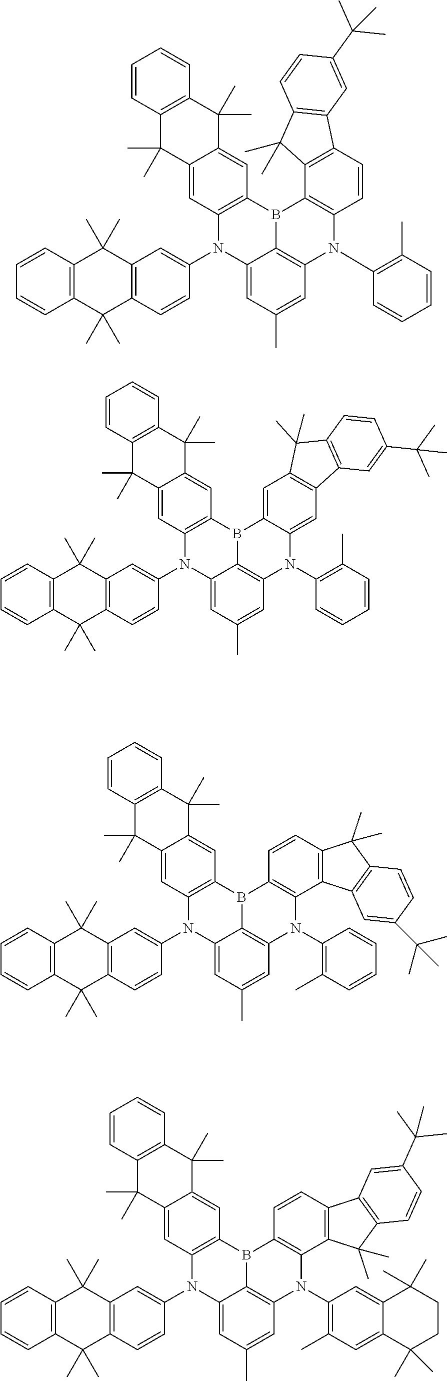

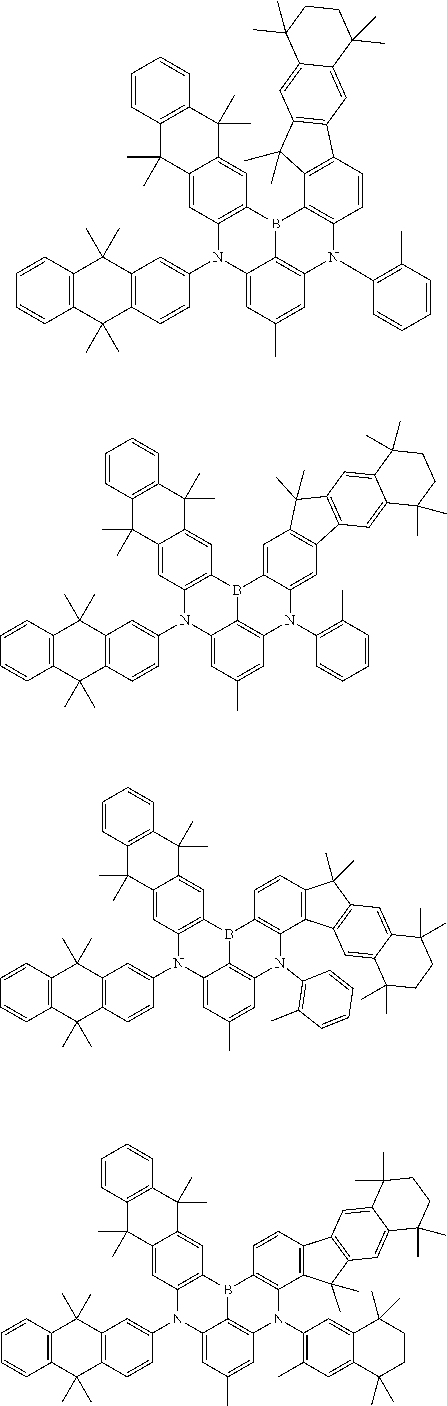

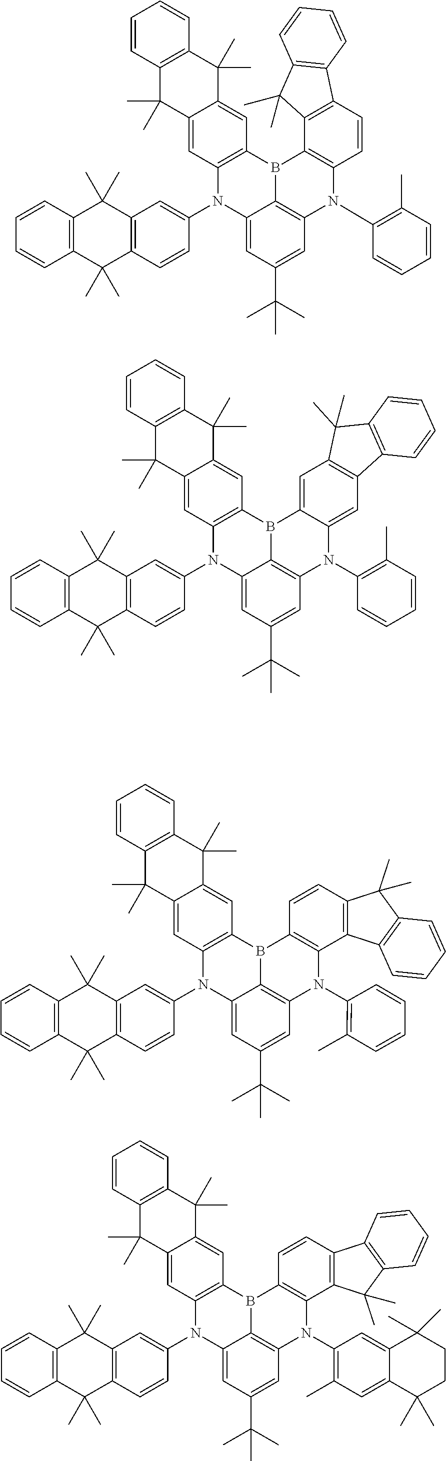

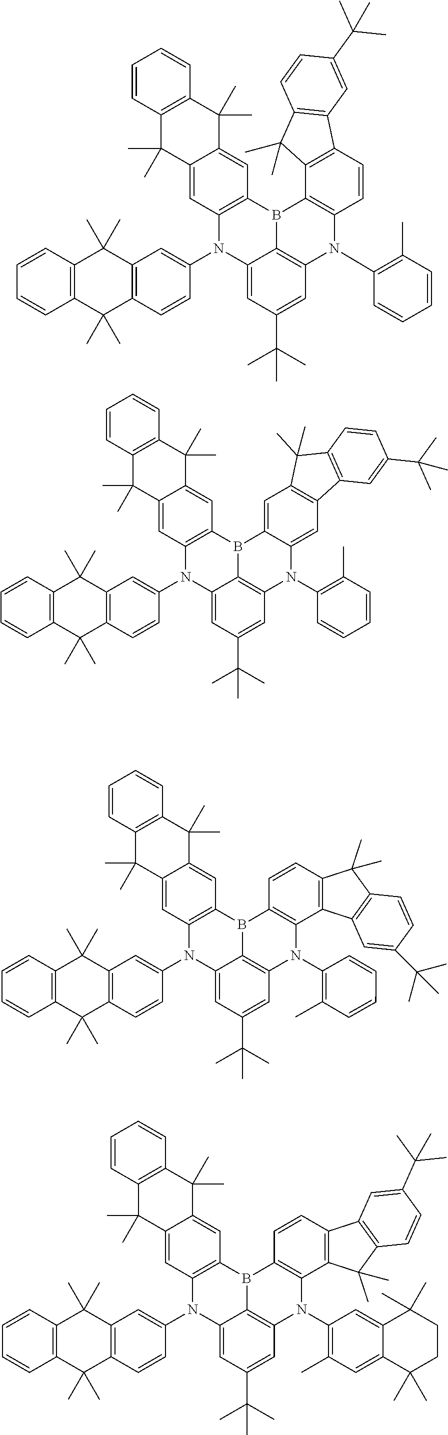

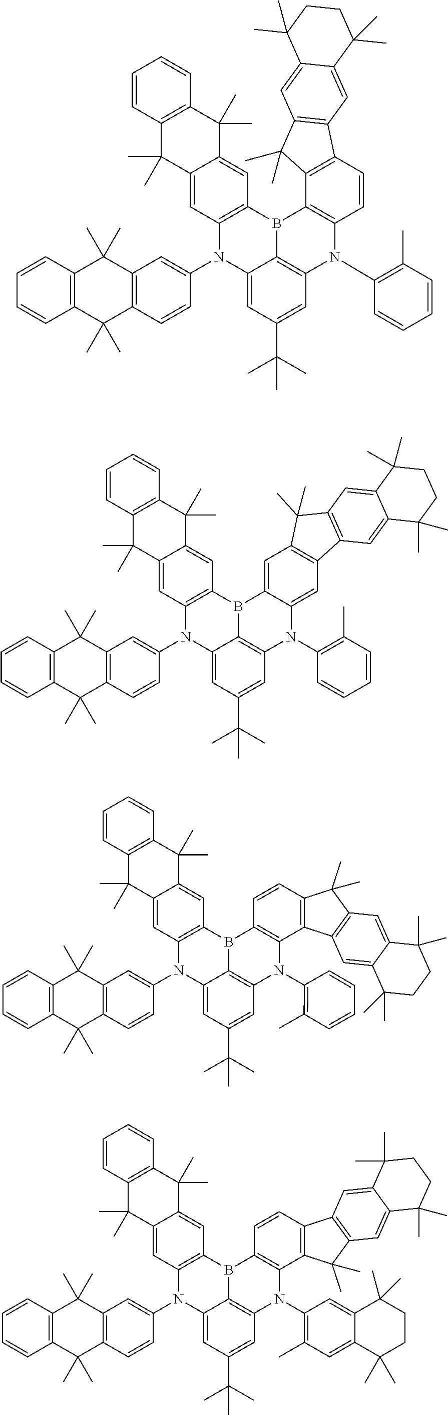

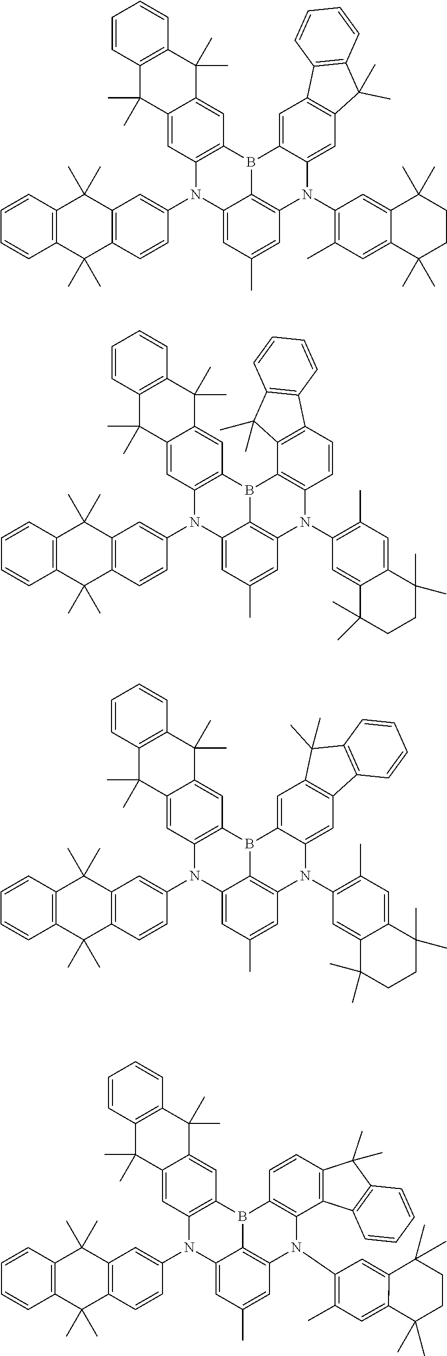

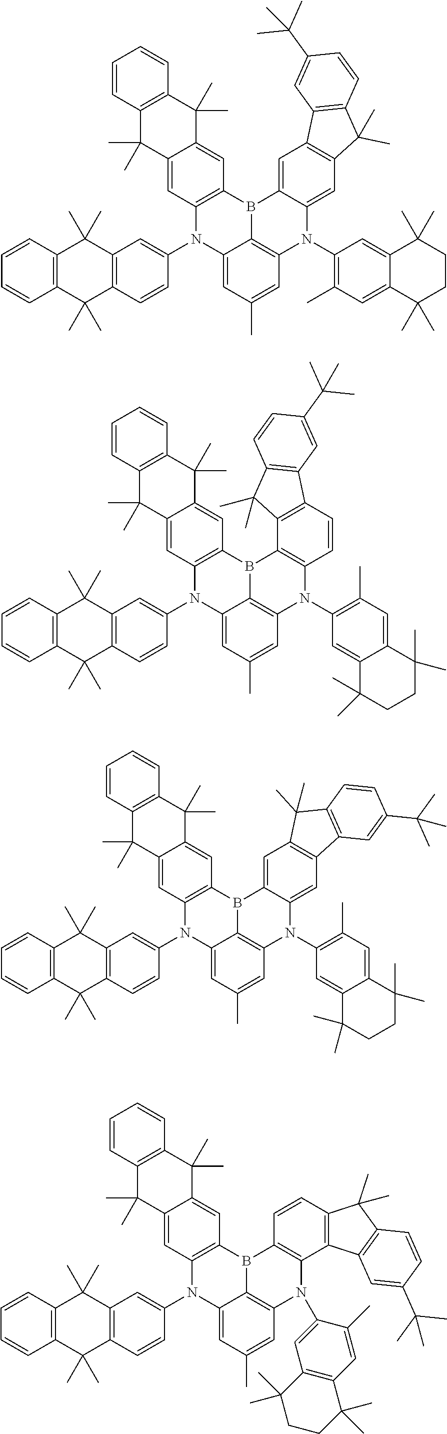

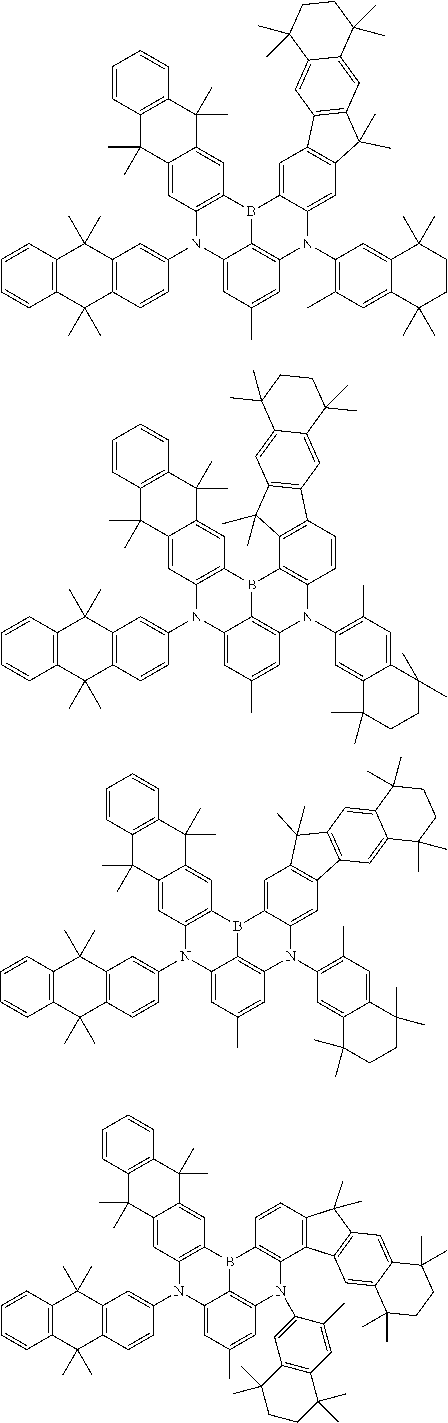

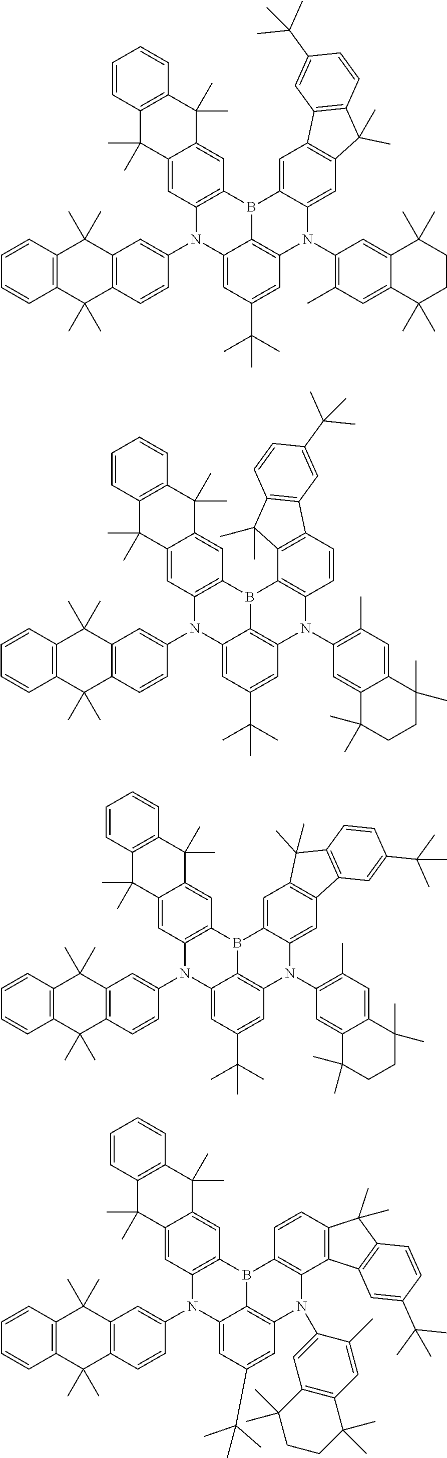

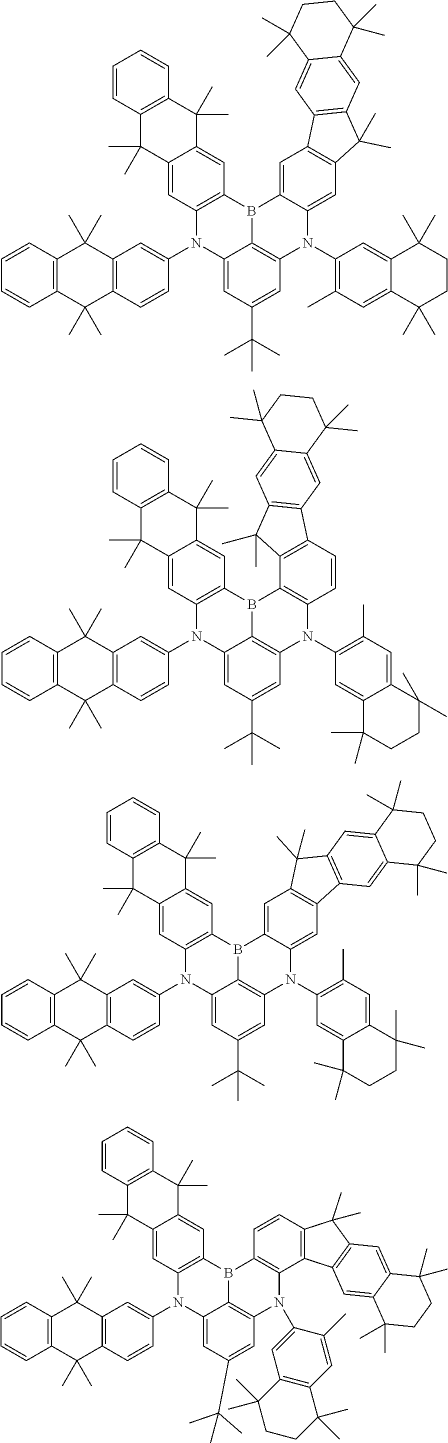

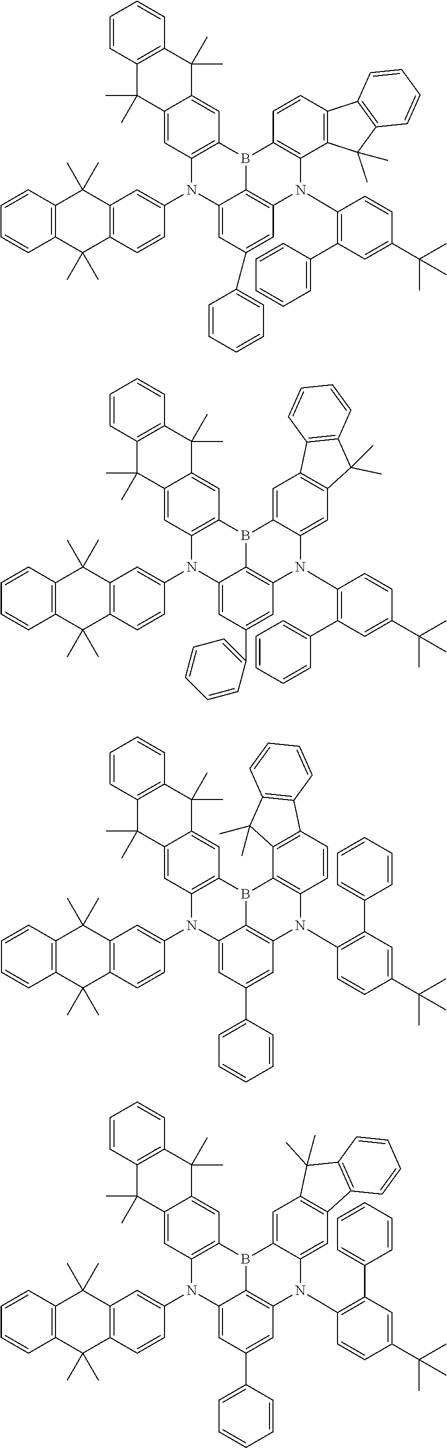

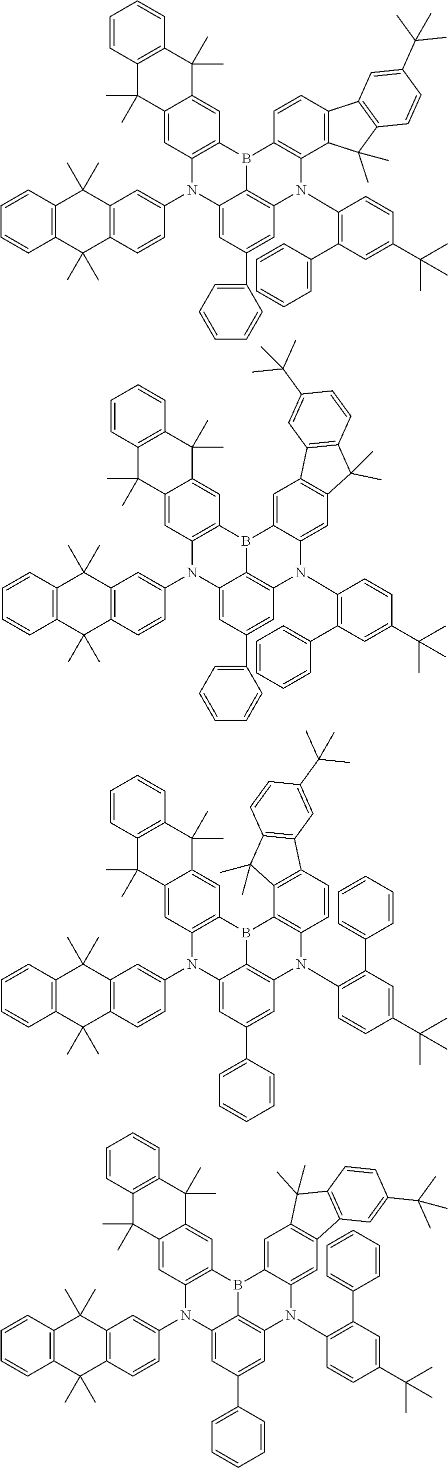

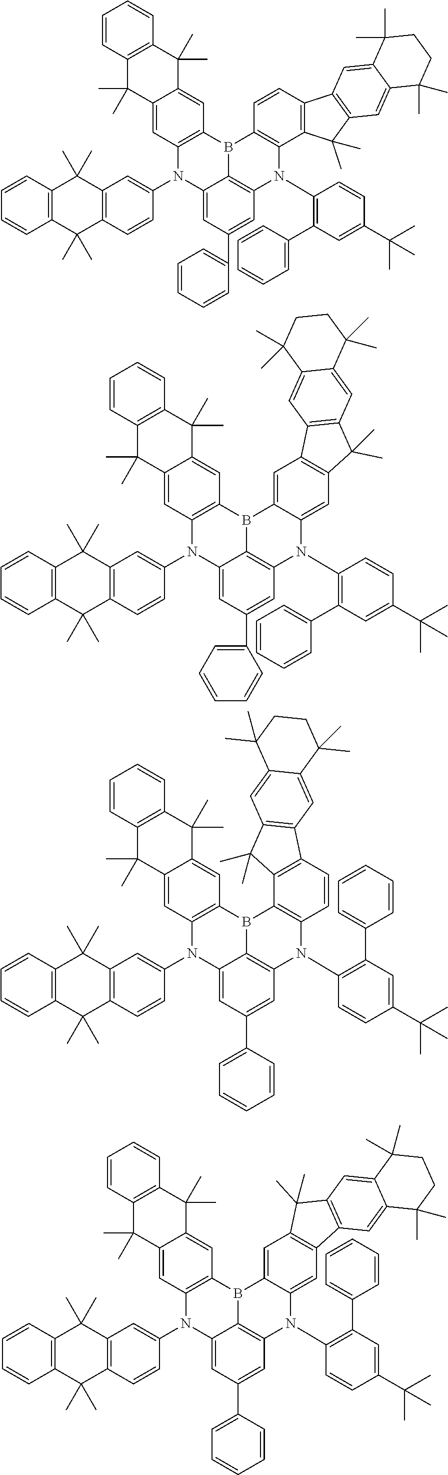

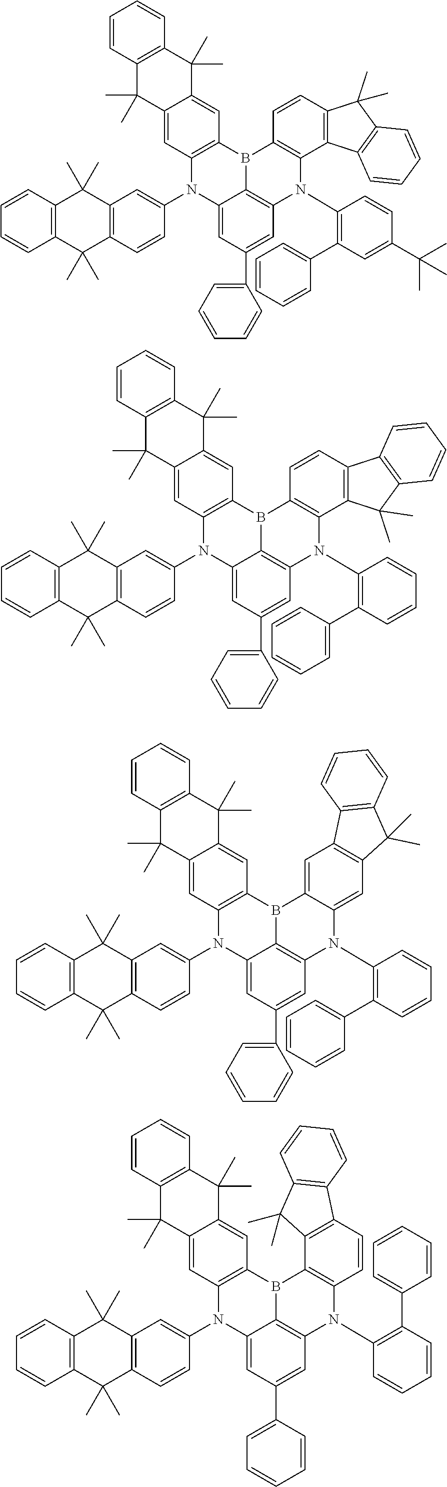

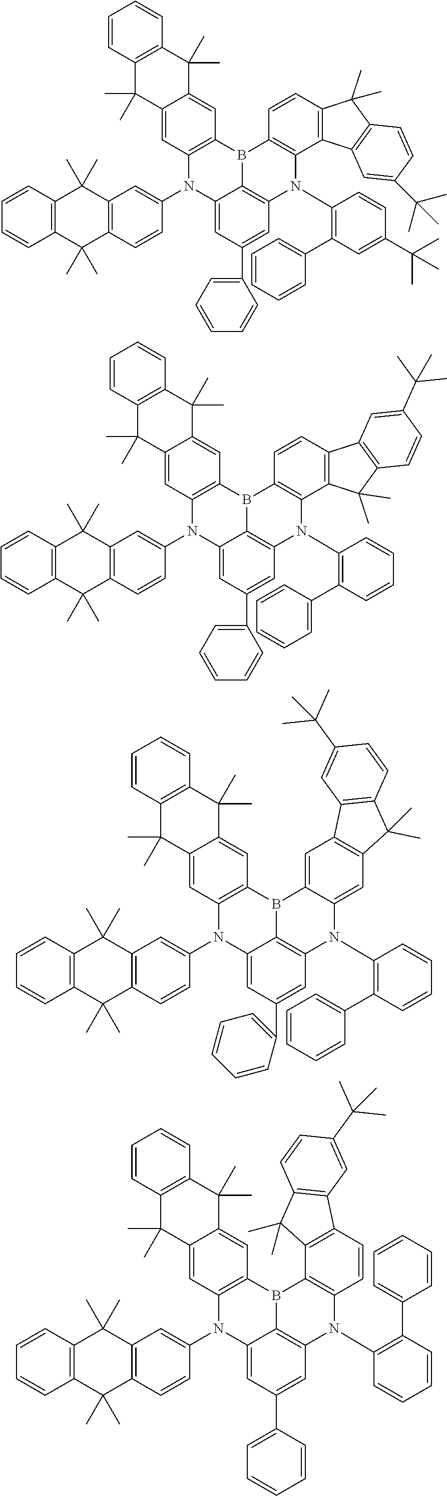

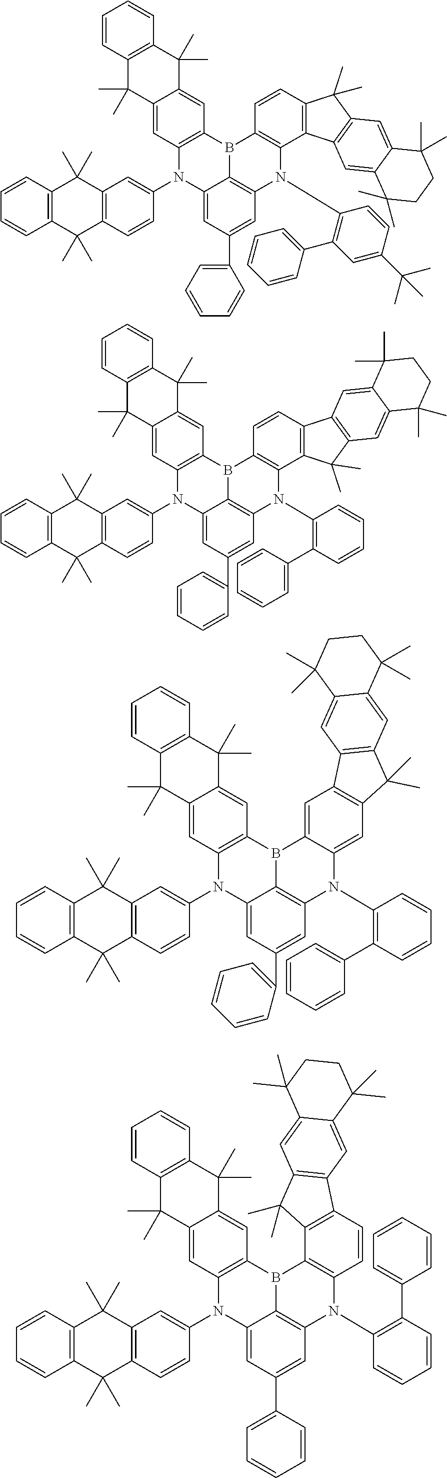

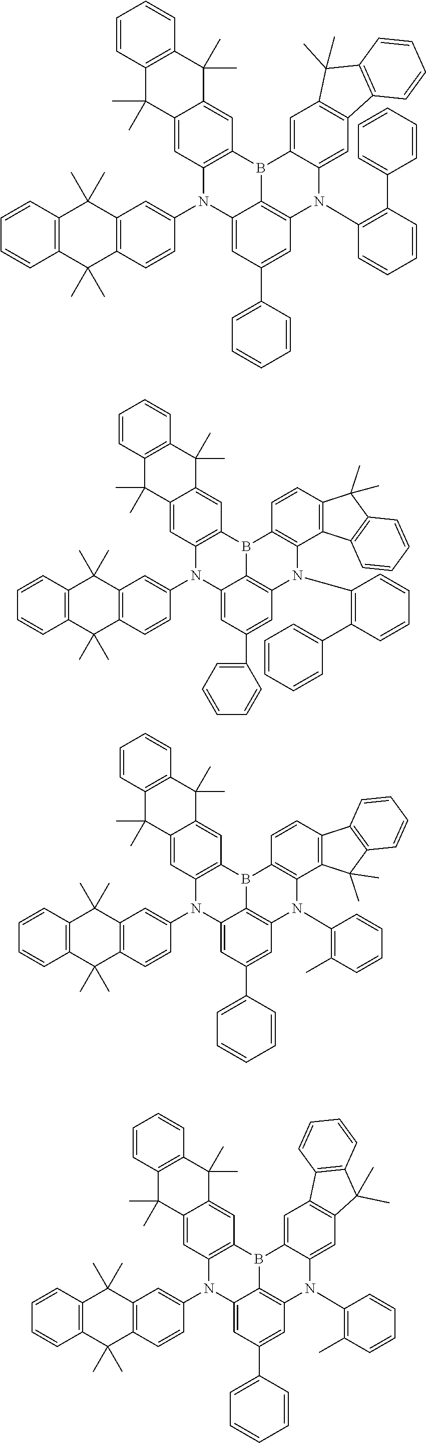

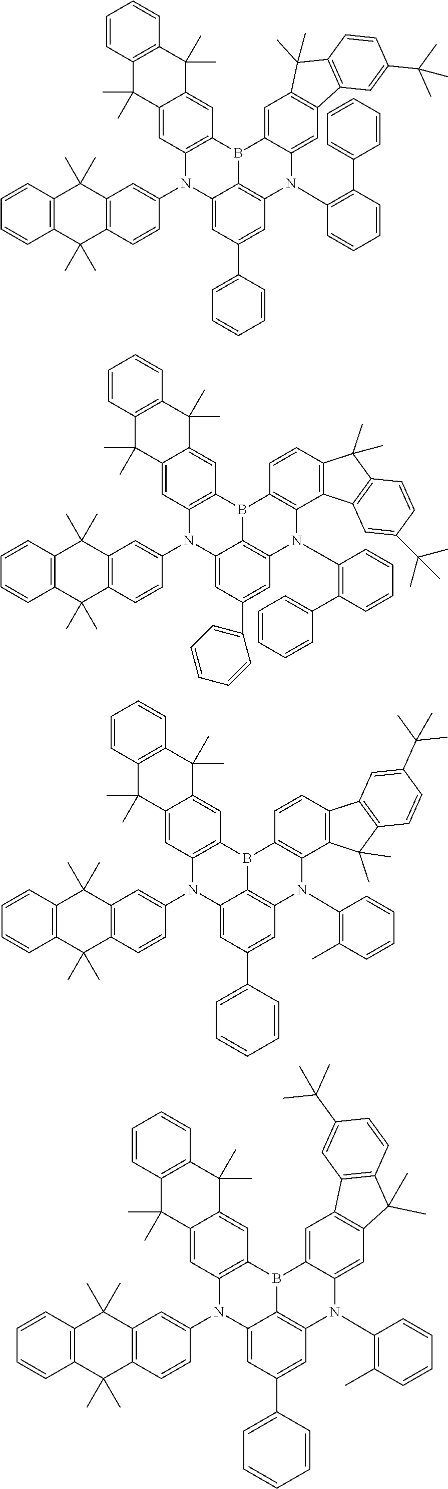

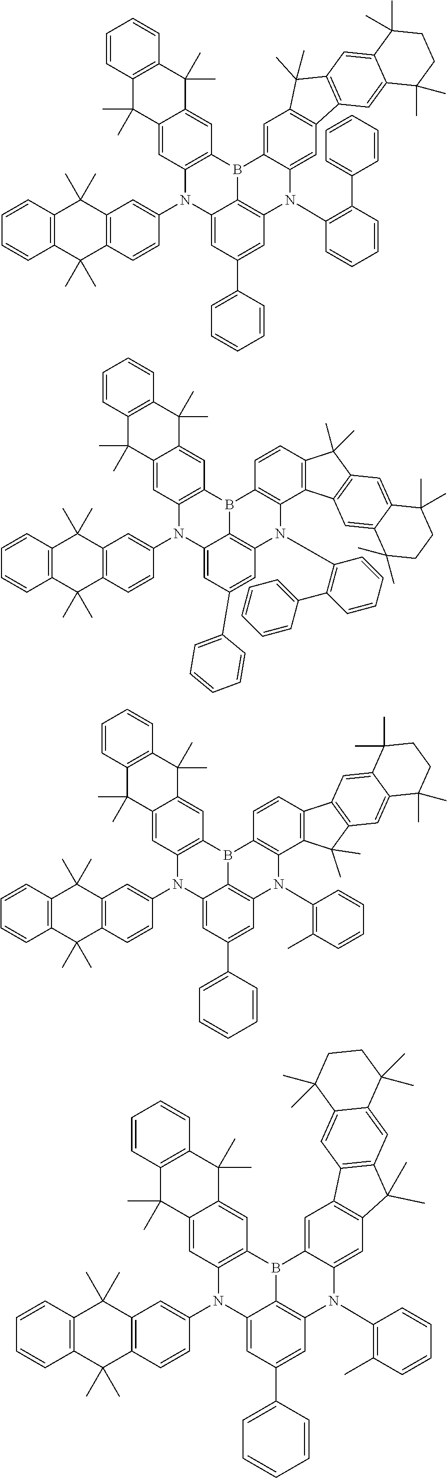

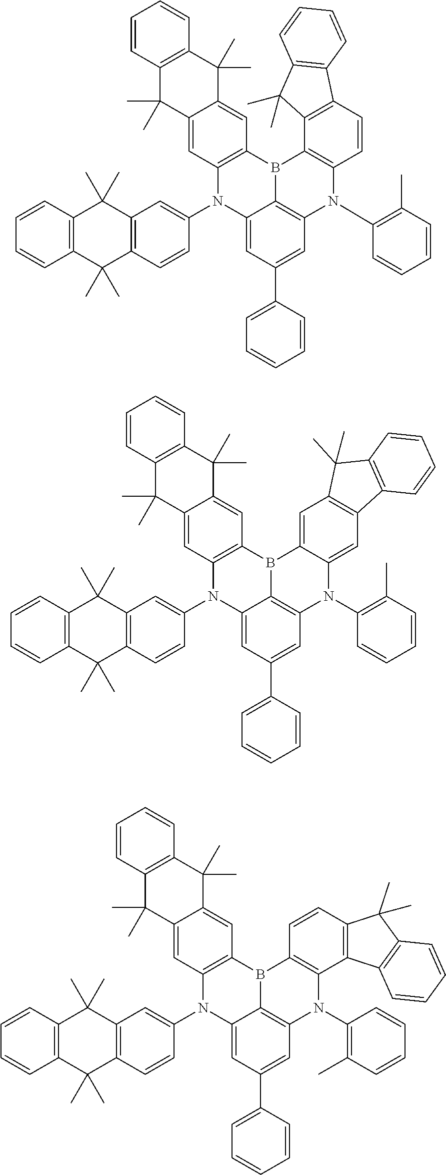 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccccc2-1 ; Cc1ccccc1N1c2cc3c(cc2B2c4cc5c(cc4N(c4ccc6c(c4)C(C)(C)c4ccccc4C6(C)C)c4cc(-c6ccccc6)cc1c42)C(C)(C)c1ccccc1C5(C)C)C(C)(C)c1ccccc1-3 ; Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(c21)-c1ccccc1C3(C)C]

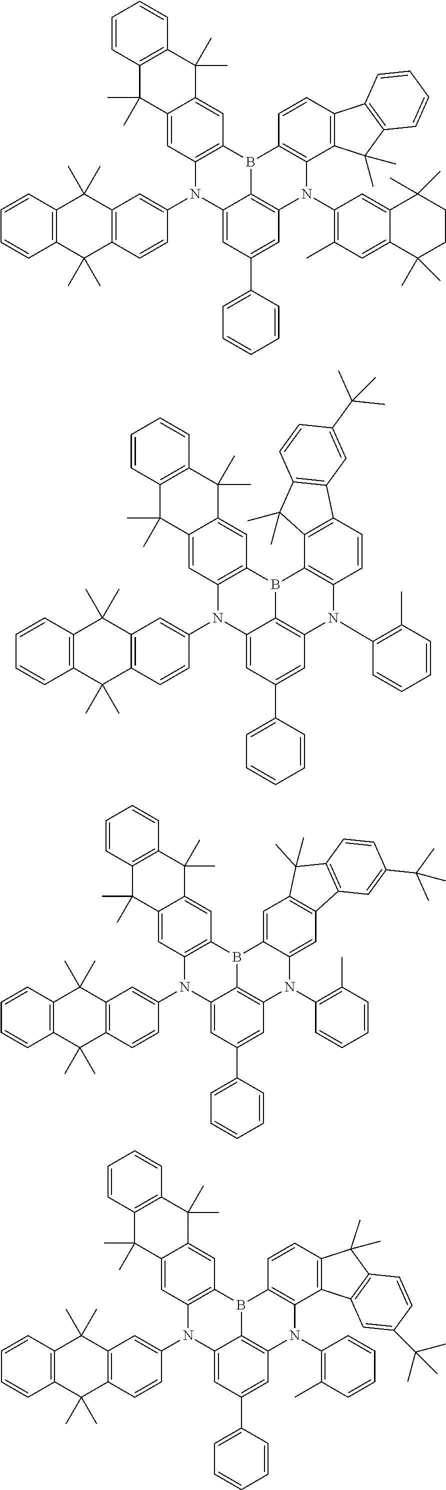

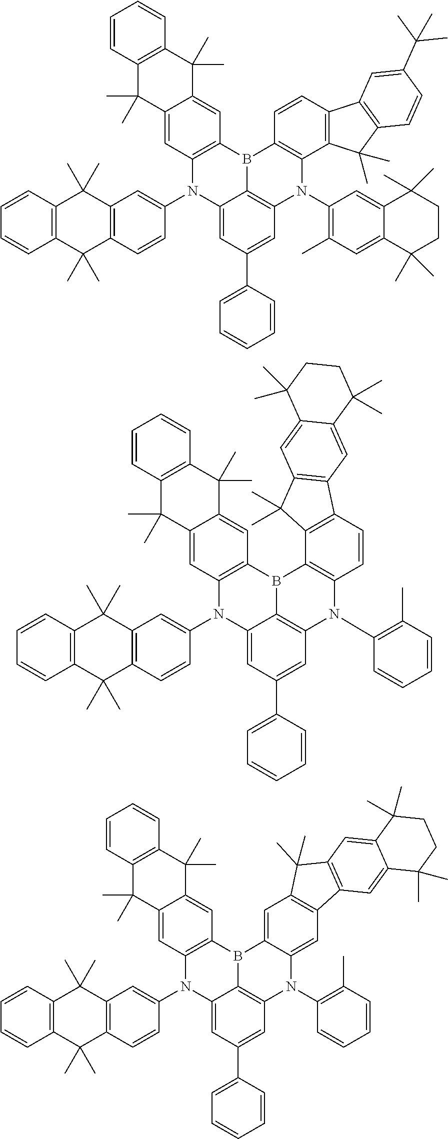

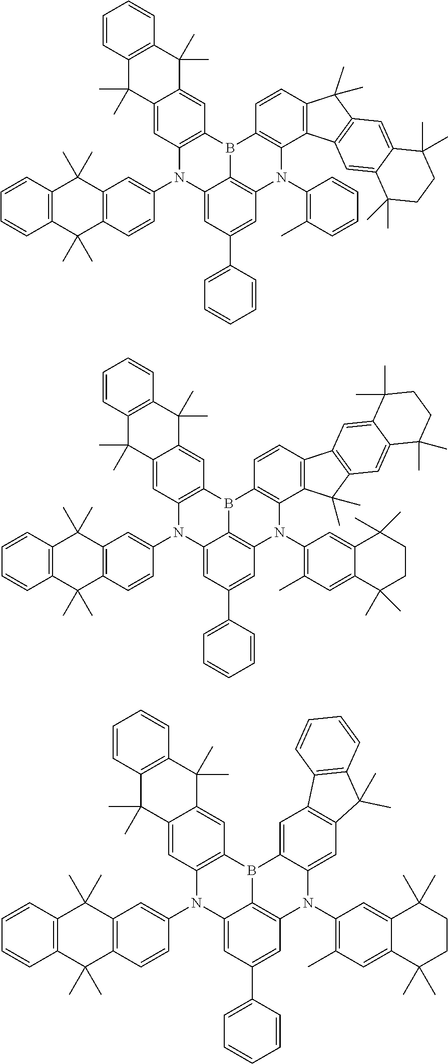 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(c21)-c1cc2c(cc1C3(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1cc3c(cc1-4)C(C)(C)CCC3(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)-c1ccccc1C4(C)C)C(C)(C)CCC2(C)C]

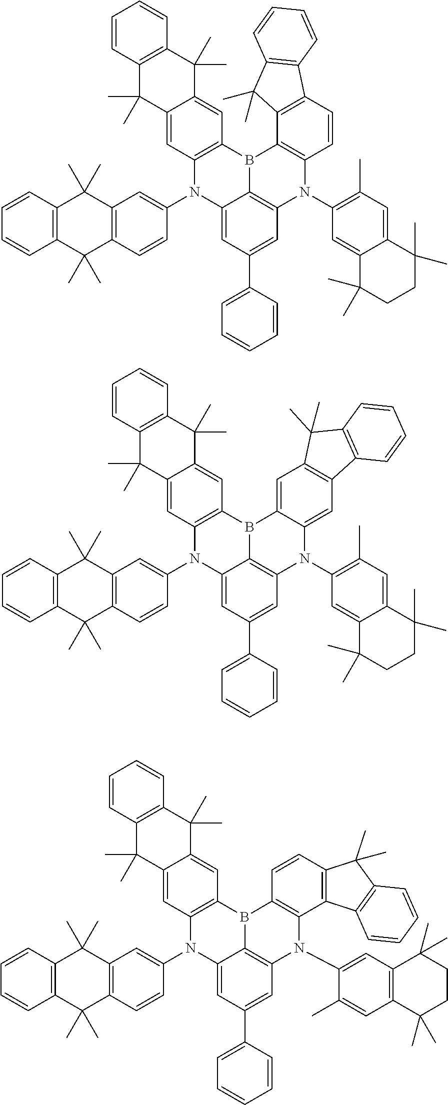 [SMILES: Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3C(C)(C)c3ccccc3-1)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)C(C)(C)c1ccccc1-4)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)-c1ccccc1C4(C)C)C(C)(C)CCC2(C)C]

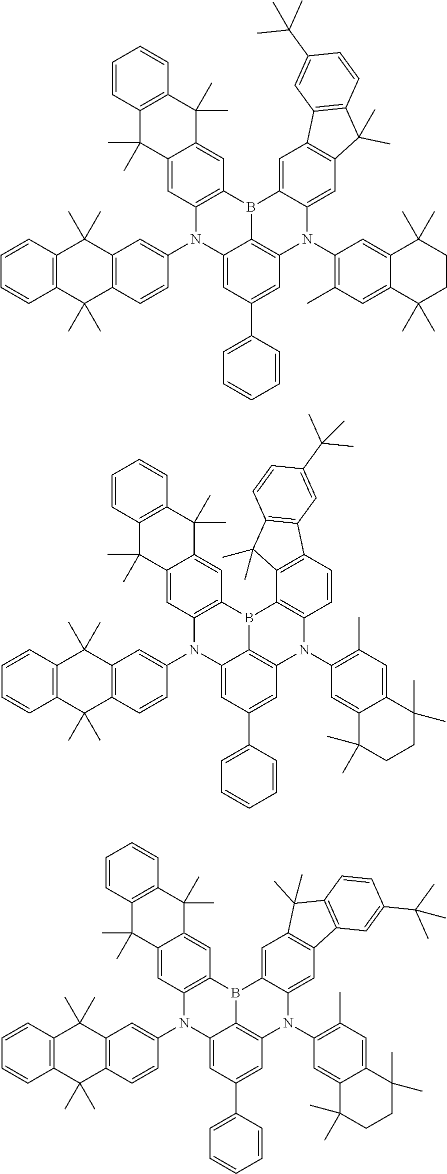

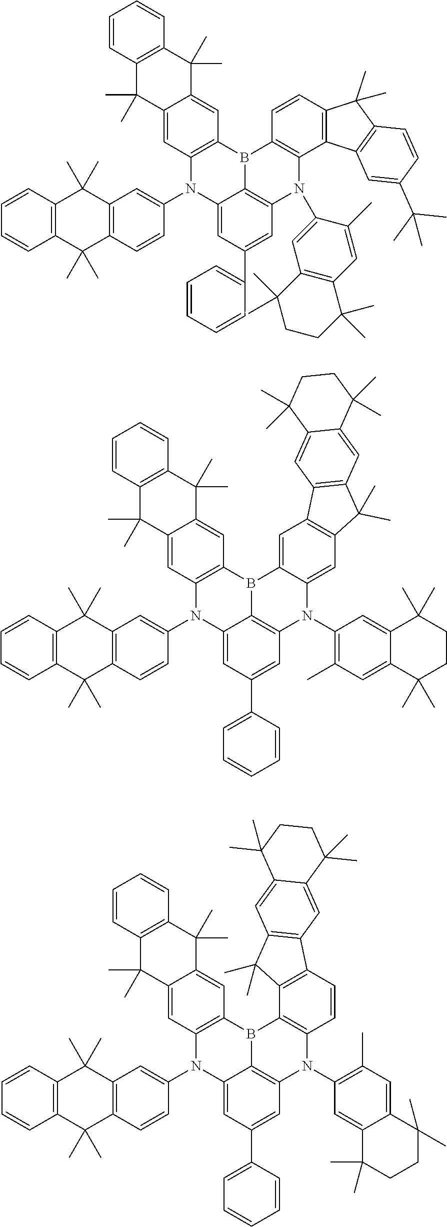

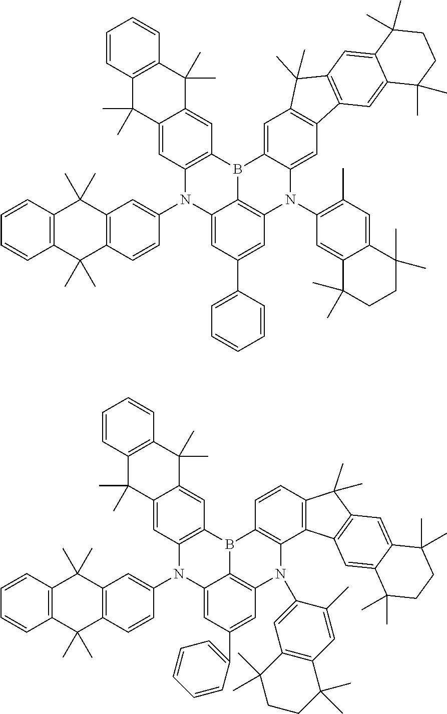 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)C(C)(C)c1cc3c(cc1-4)C(C)(C)CCC3(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)-c1cc3c(cc1C4(C)C)C(C)(C)CCC3(C)C)C(C)(C)CCC2(C)C]

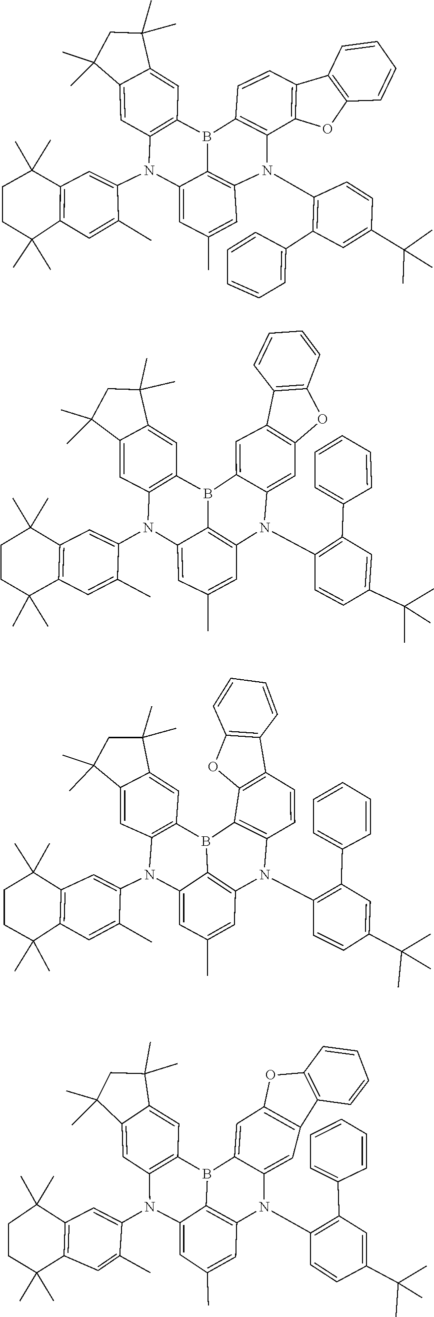

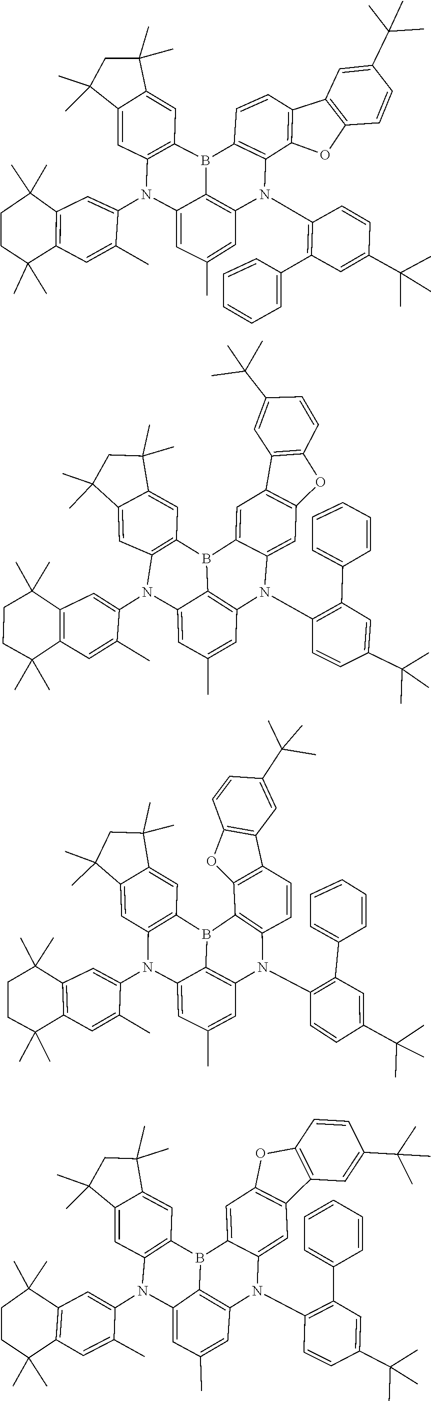

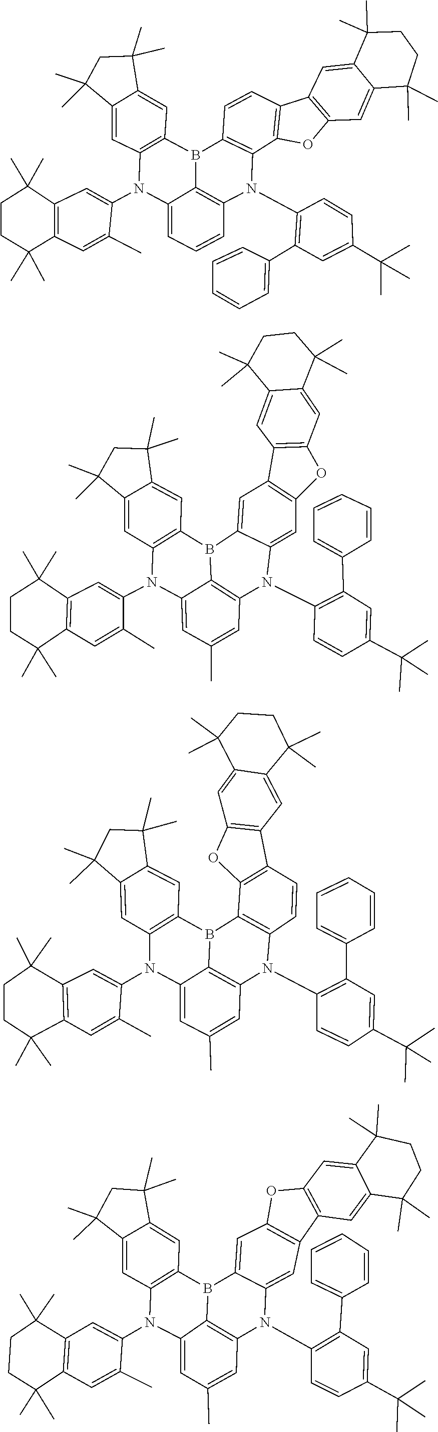

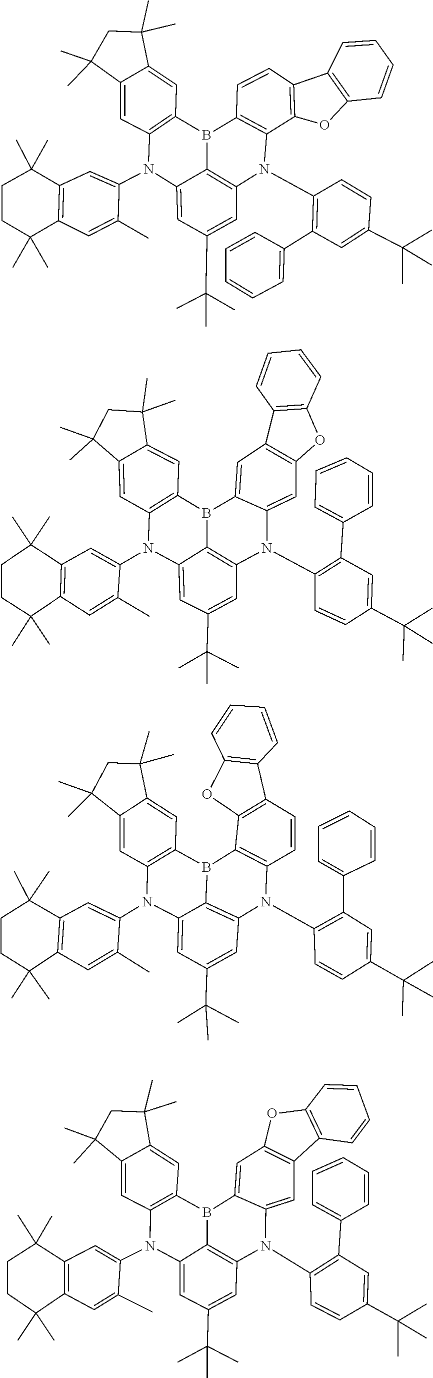

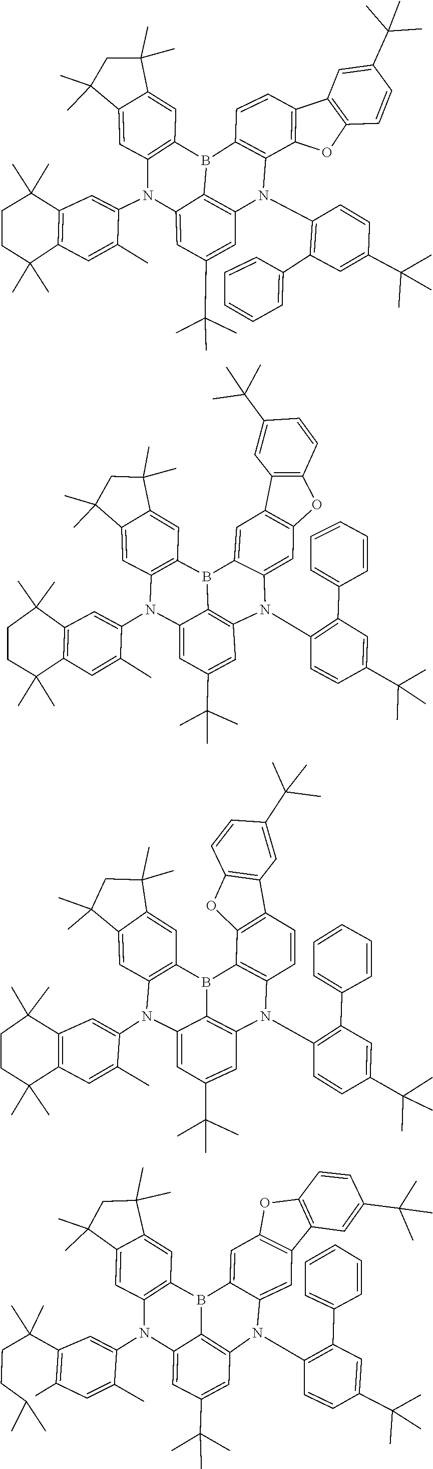

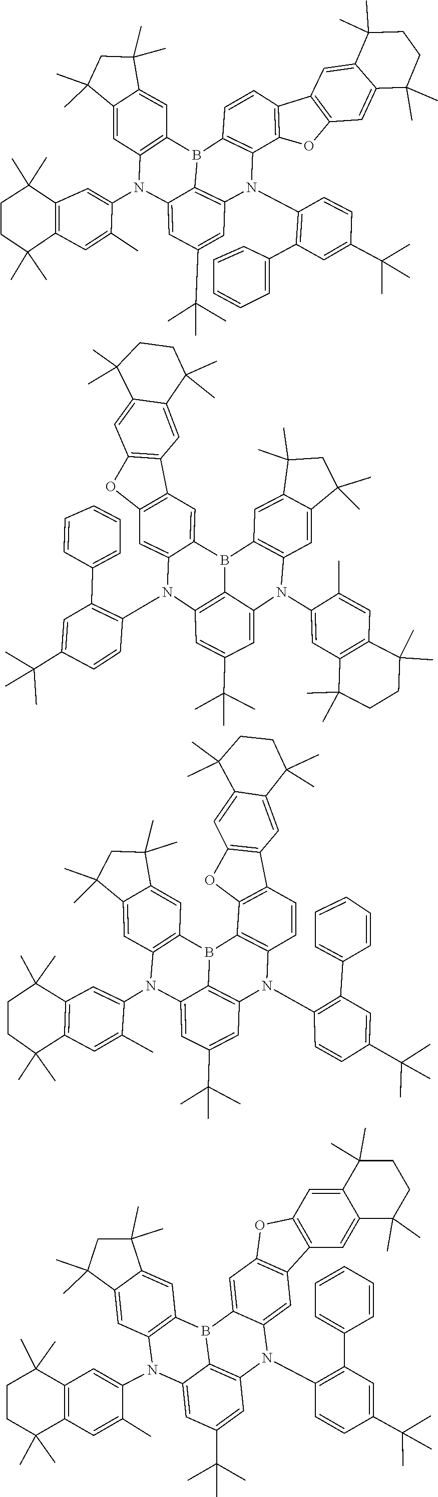

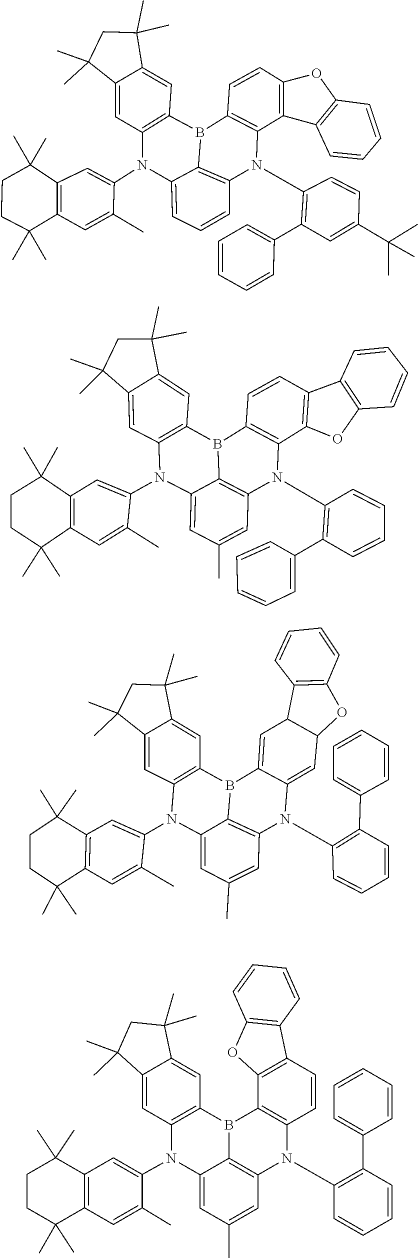

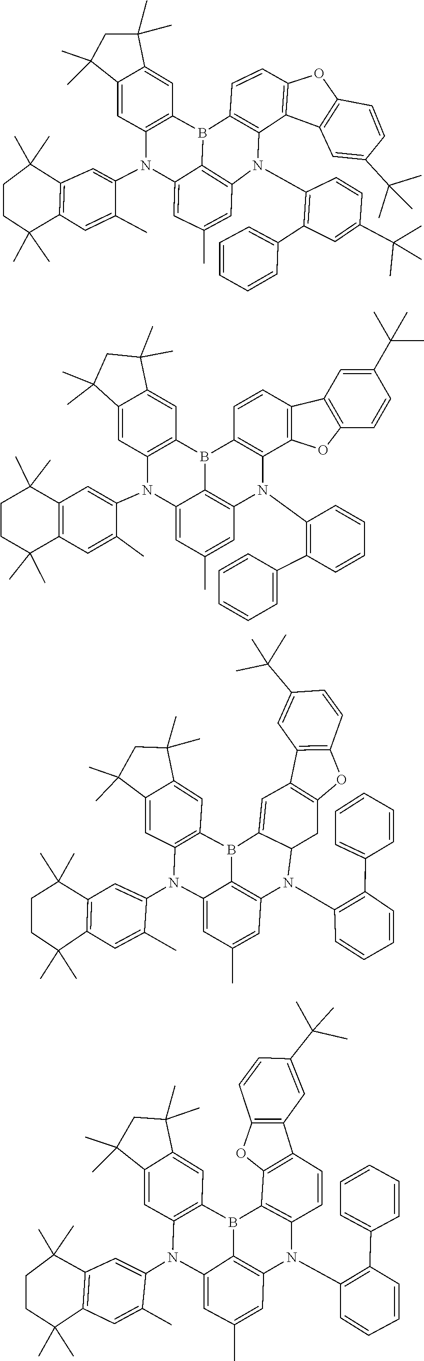

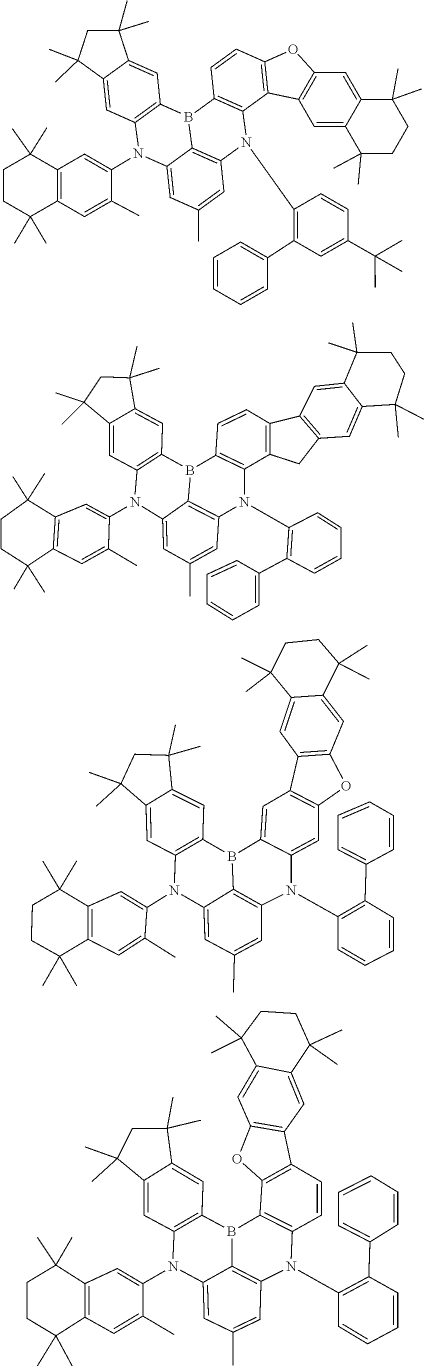

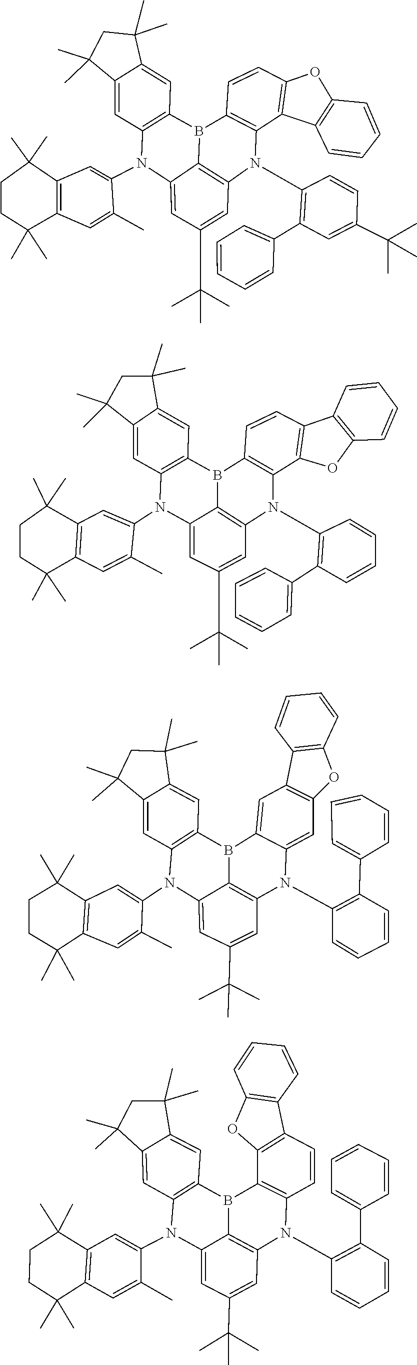

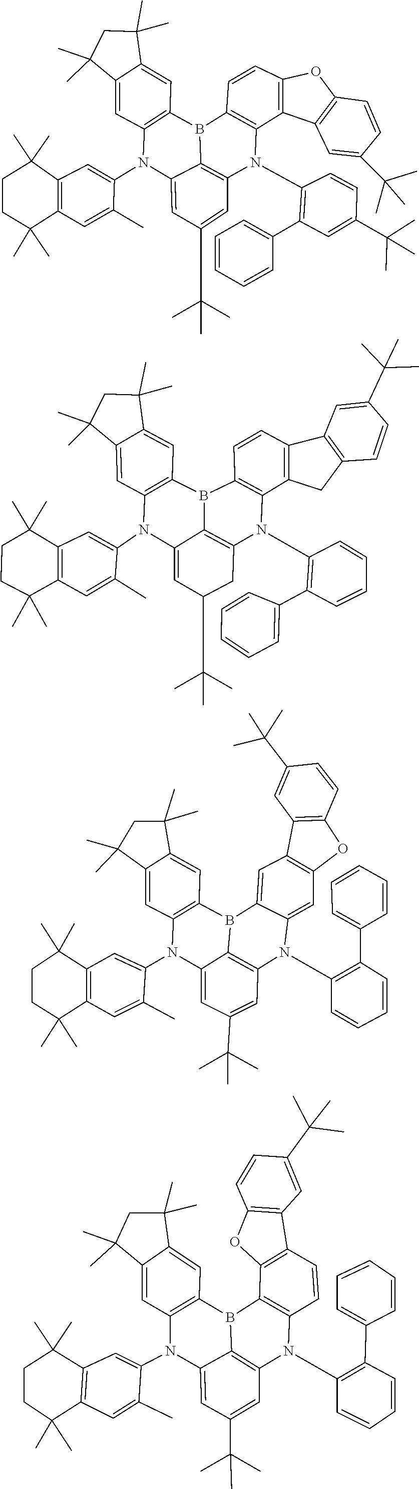

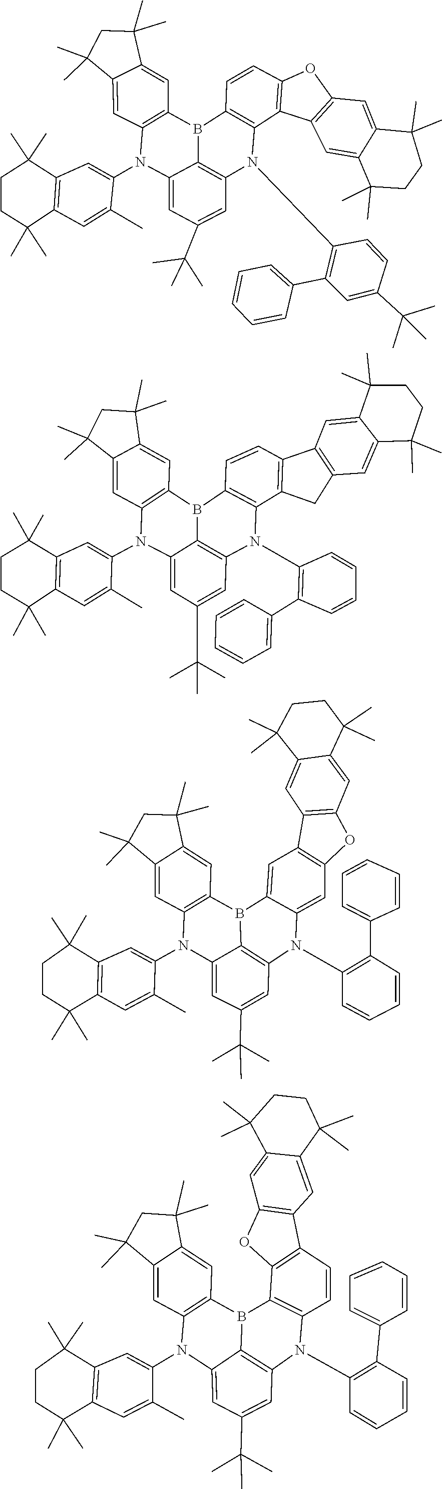

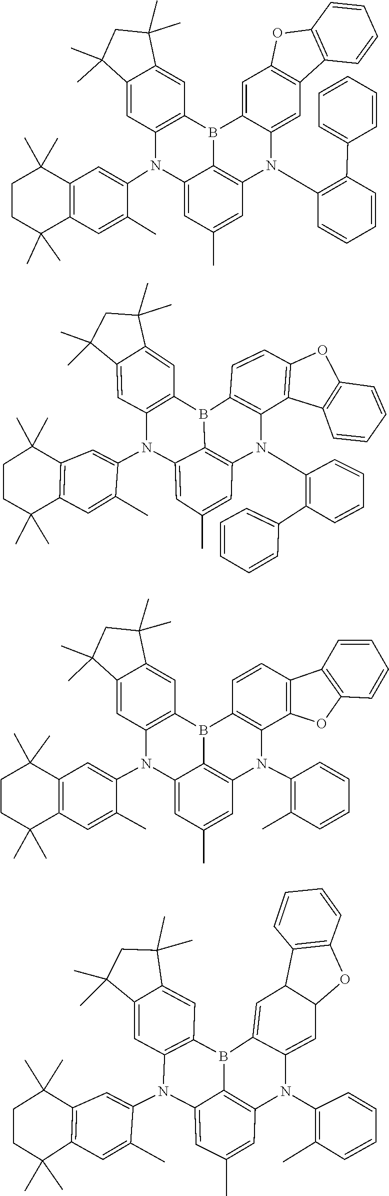 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)oc1ccccc14 ; Cc1cc2c3c(c1)N(c1ccccc1-c1ccccc1)c1c(ccc4oc5ccccc5c14)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1oc1ccccc14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1cc4c(cc1B3C1=CC3c5ccccc5OC3C=C1N2c1ccccc1C)C(C)(C)CC4(C)C]

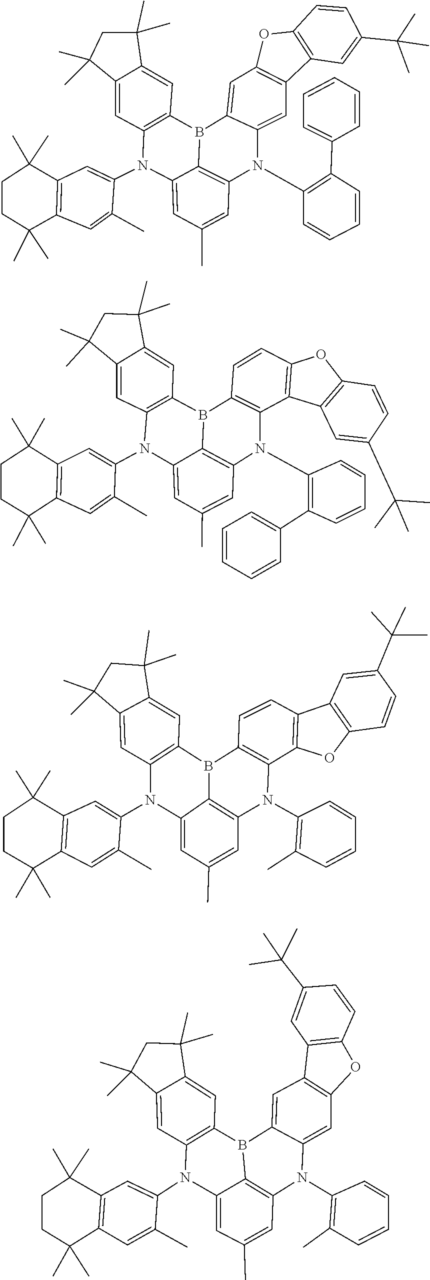 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)oc1ccc(C(C)(C)C)cc14 ; Cc1cc2c3c(c1)N(c1ccccc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1oc1ccc(C(C)(C)C)cc14)B3c1cc3c(cc1N2c1cc2c(cc1C)C(C)(C)CCC2(C)C)C(C)(C)CC3(C)C ; Cc1cc2c3c(c1)N(c1ccccc1C)c1cc4oc5ccc(C(C)(C)C)cc5c4cc1B3c1cc3c(cc1N2c1cc2c(cc1C)C(C)(C)CCC2(C)C)C(C)(C)CC3(C)C]

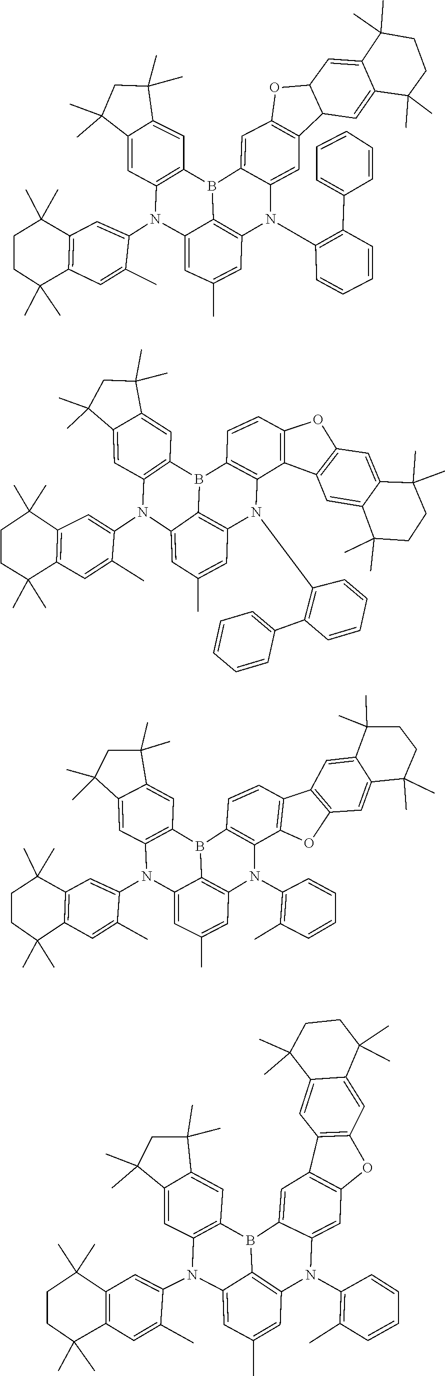

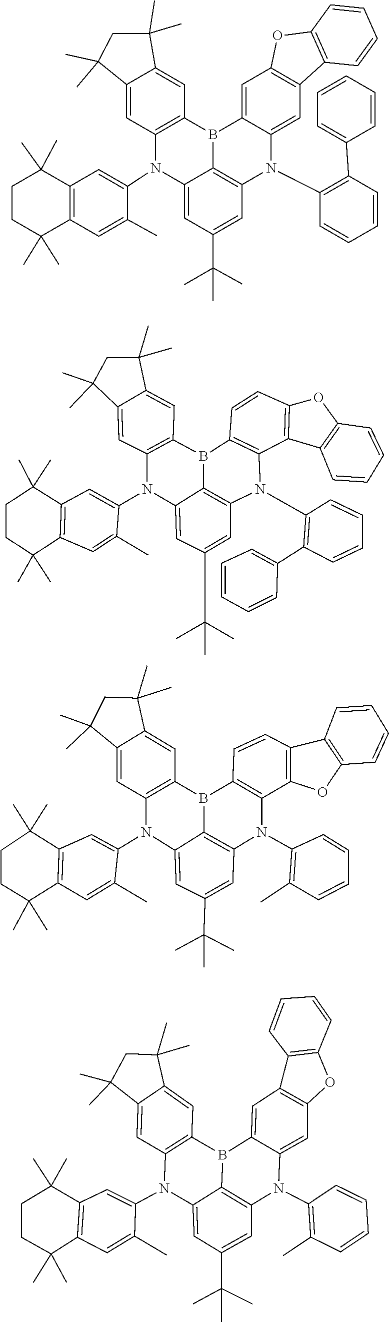

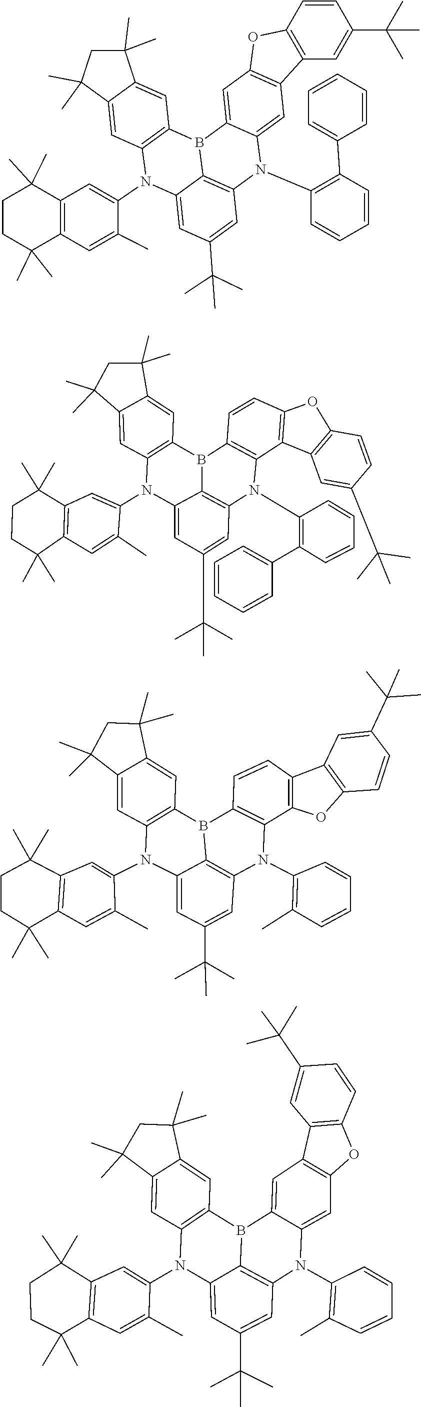

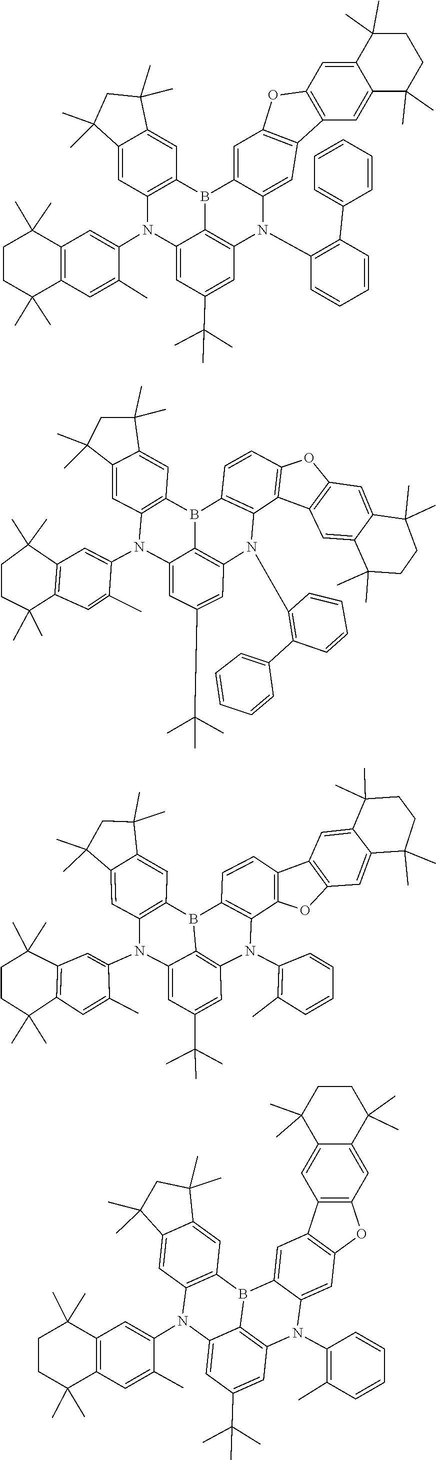

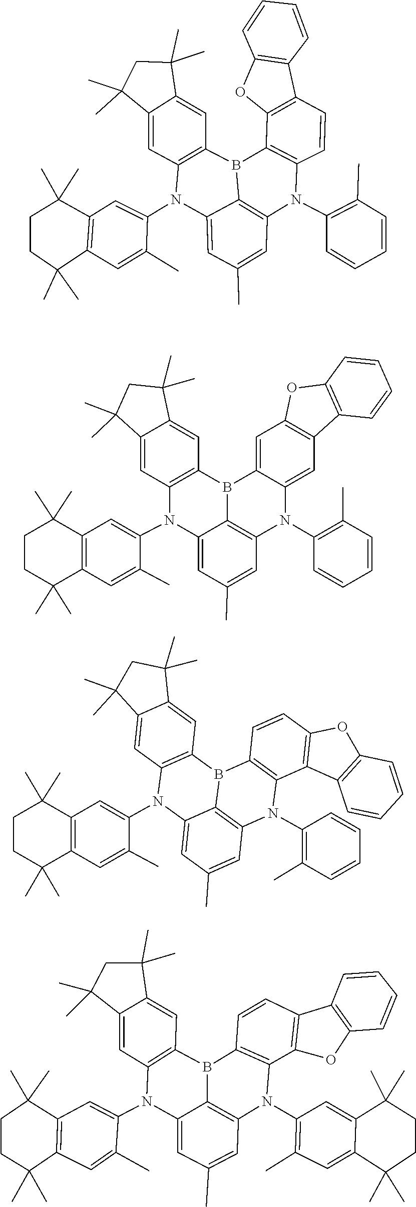 [SMILES: Cc1cc2c3c(c1)N(c1ccccc1C)c1ccc4c(oc5ccccc54)c1B3c1cc3c(cc1N2c1cc2c(cc1C)C(C)(C)CCC2(C)C)C(C)(C)CC3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1ccccc14 ; Cc1cc2c3c(c1)N(c1ccccc1C)c1c(ccc4oc5ccccc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)CC3(C)C]

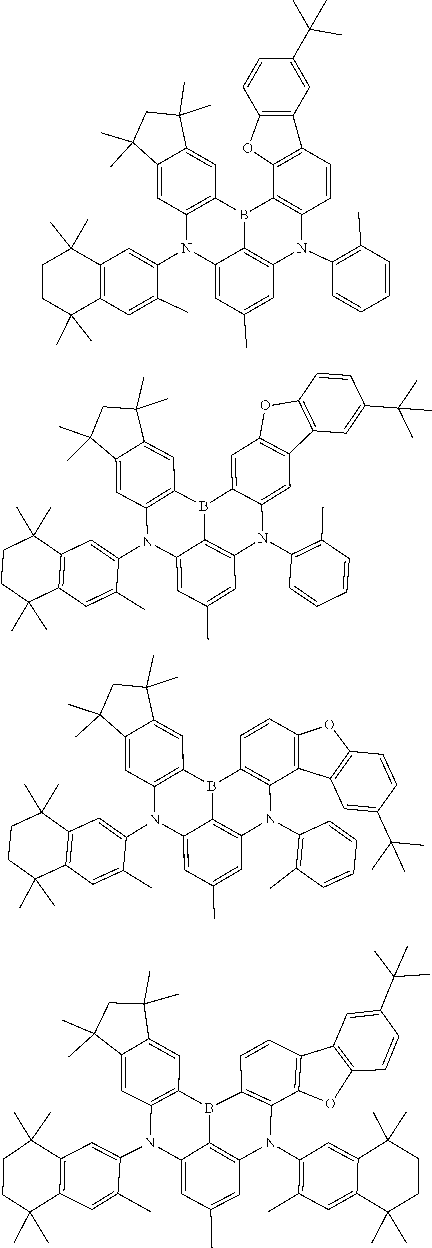

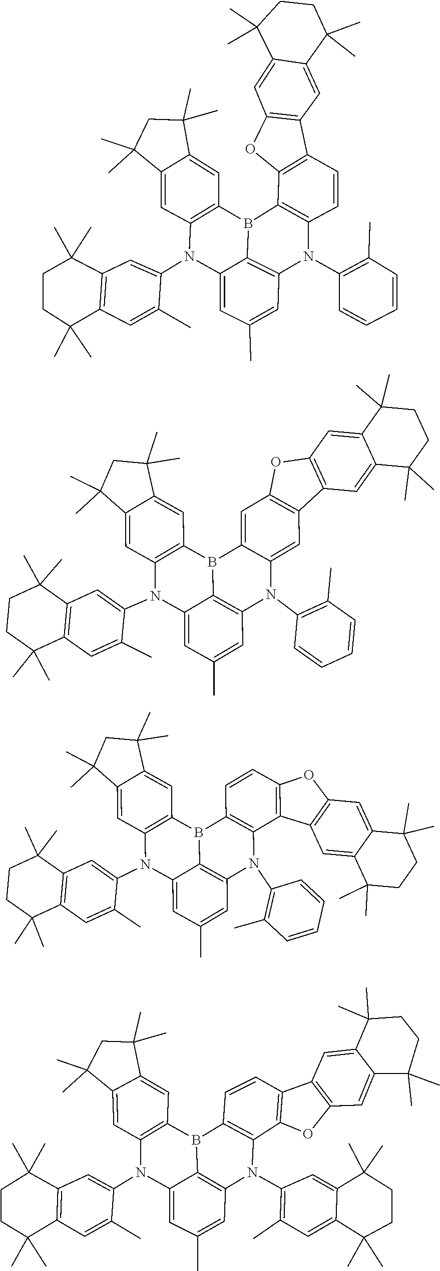

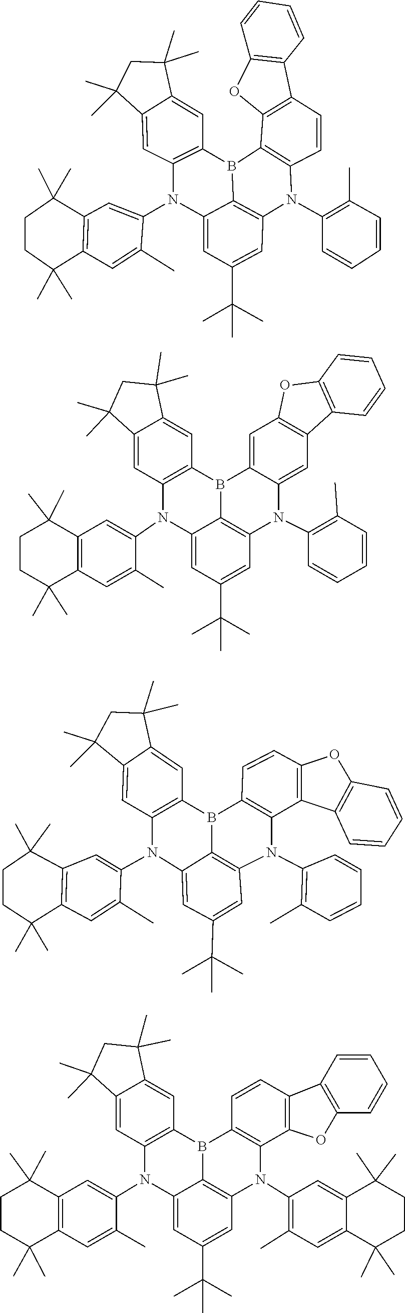 [SMILES: Cc1cc2c(cc1N1c3cc4c(cc3B3c5c1cc(C(C)(C)C)cc5N(c1ccccc1C)c1ccc5c(oc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)oc1ccccc13 ; Cc1cc2c(cc1N1c3cc4c(cc3B3c5ccc6oc7ccccc7c6c5N(c5ccccc5C)c5cc(C(C)(C)C)cc1c53)C(C)(C)CC4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(C(C)(C)C)cc1c53)C(C)(C)CC4(C)C)C(C)(C)CCC2(C)C]

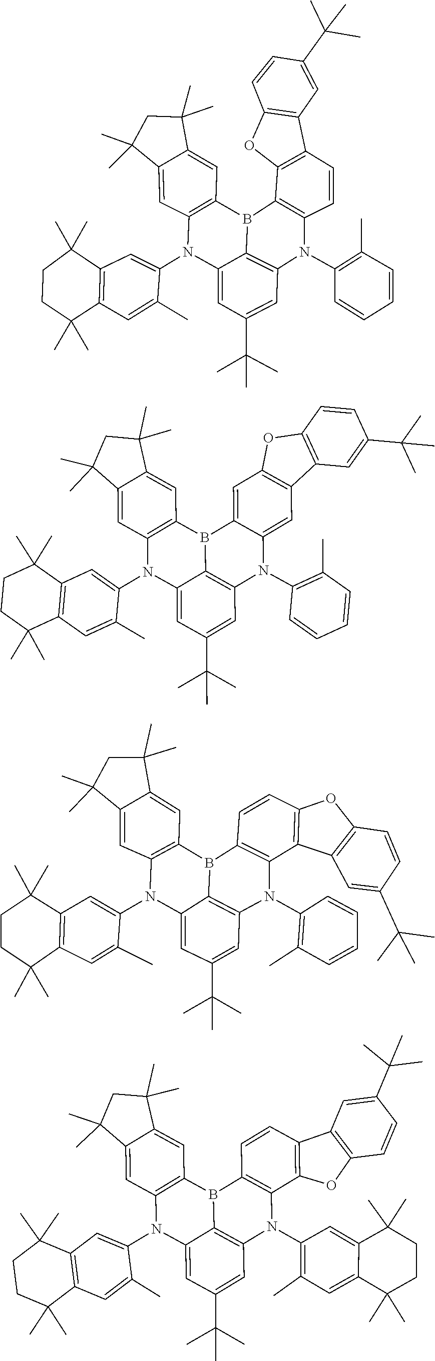

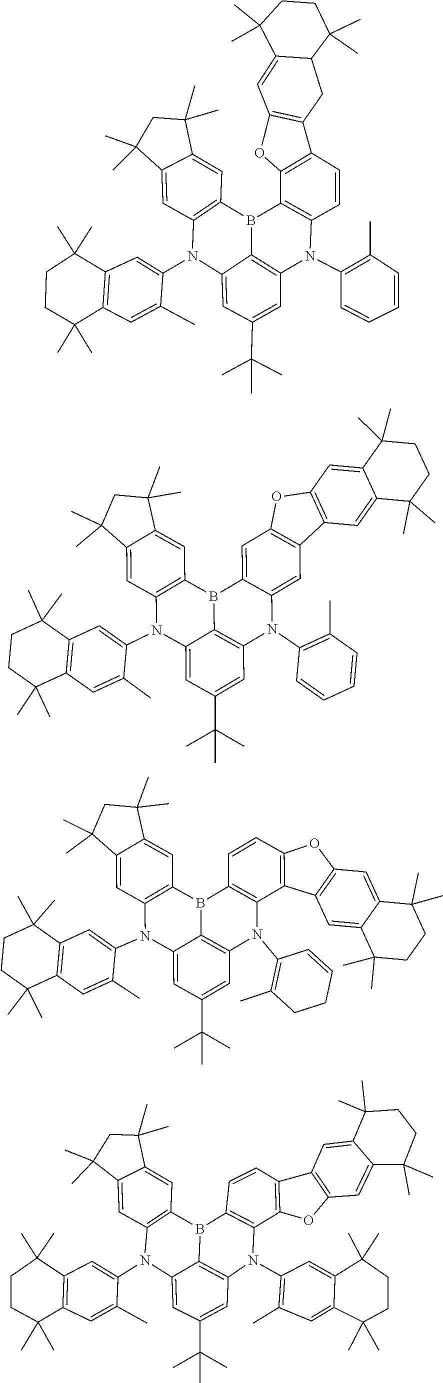

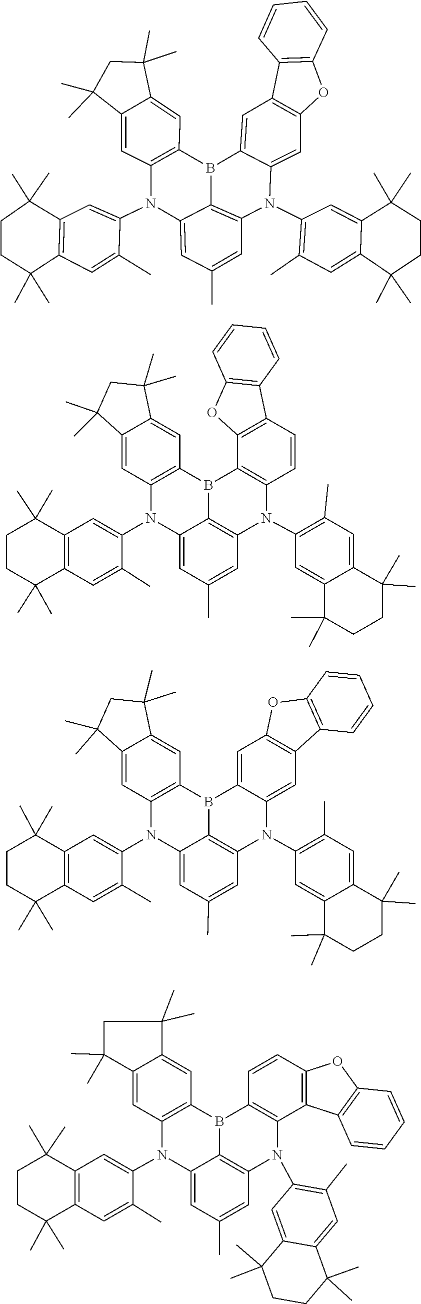

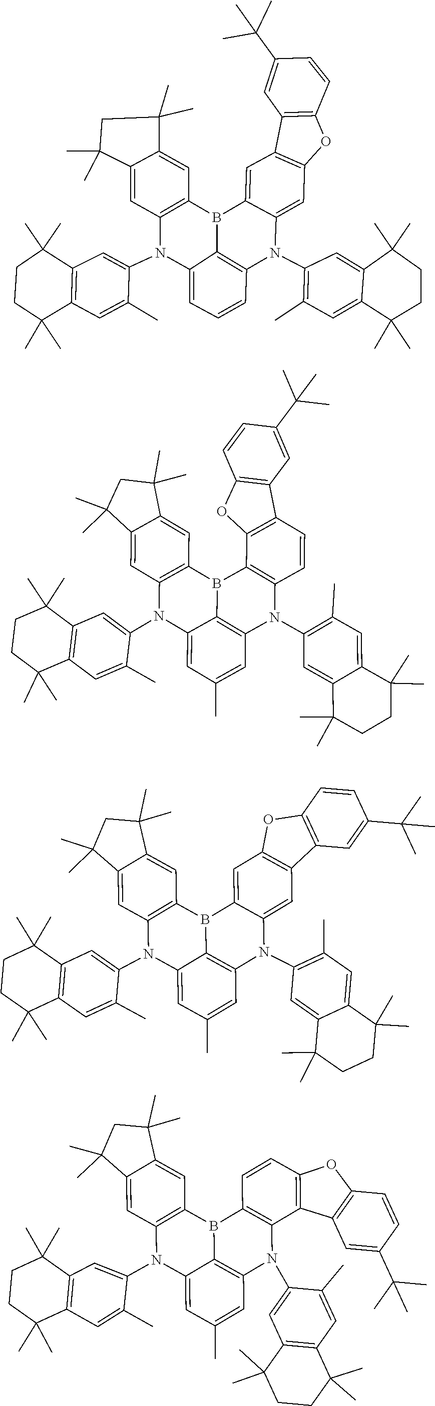

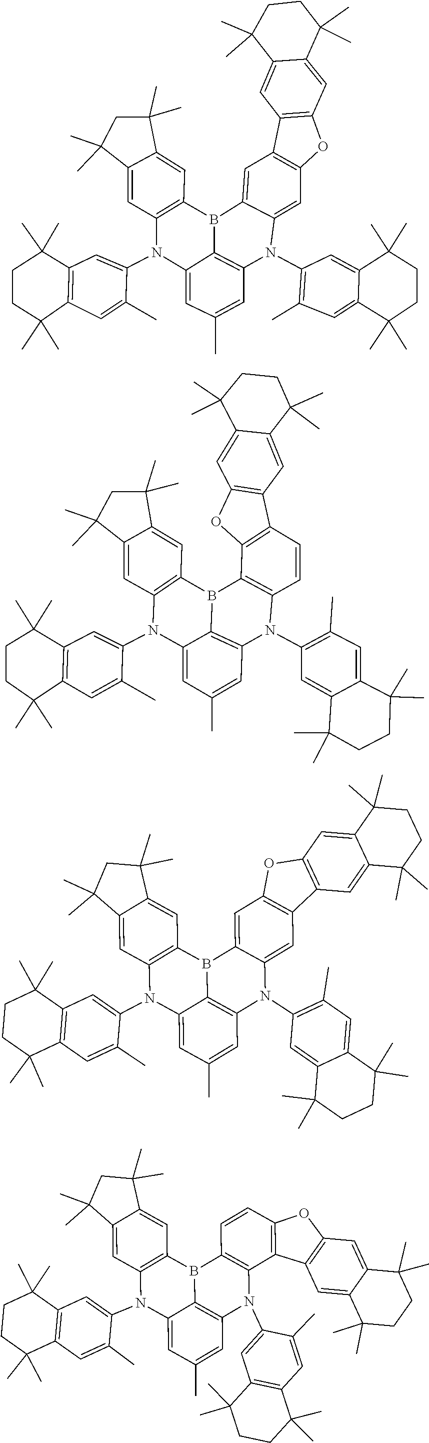

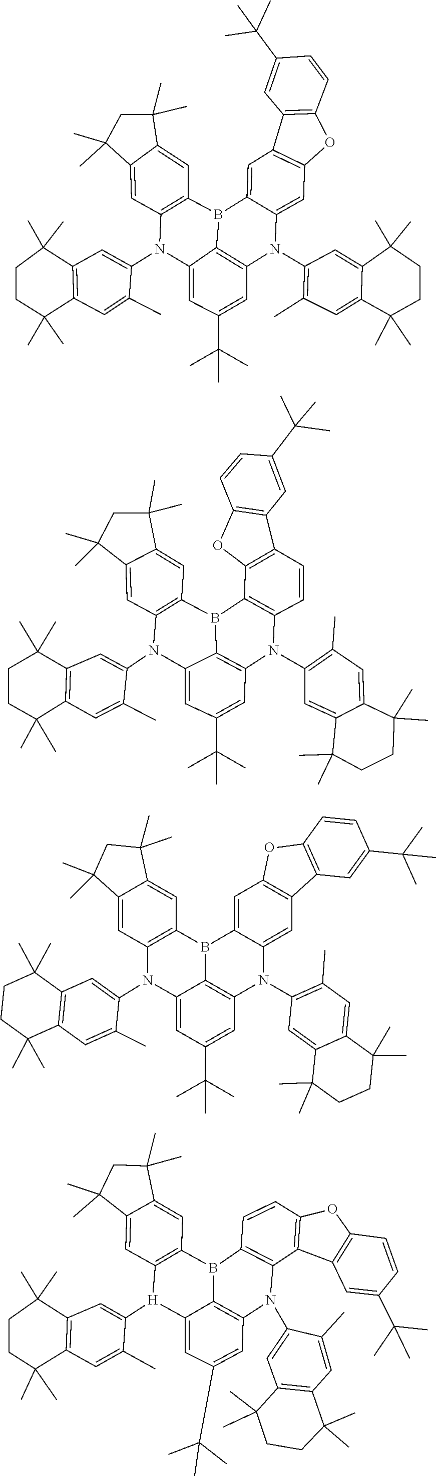

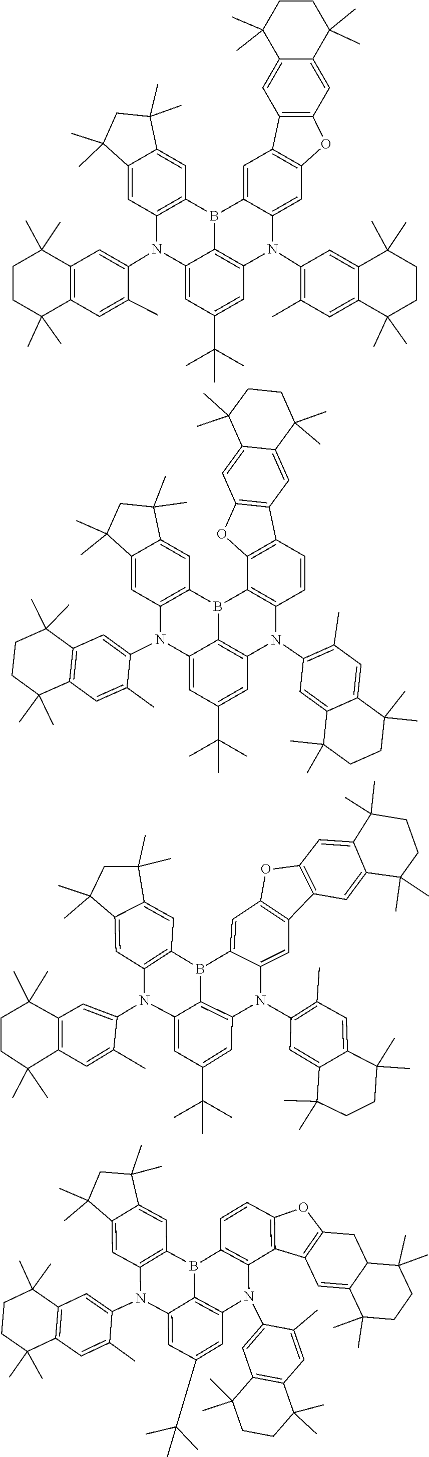

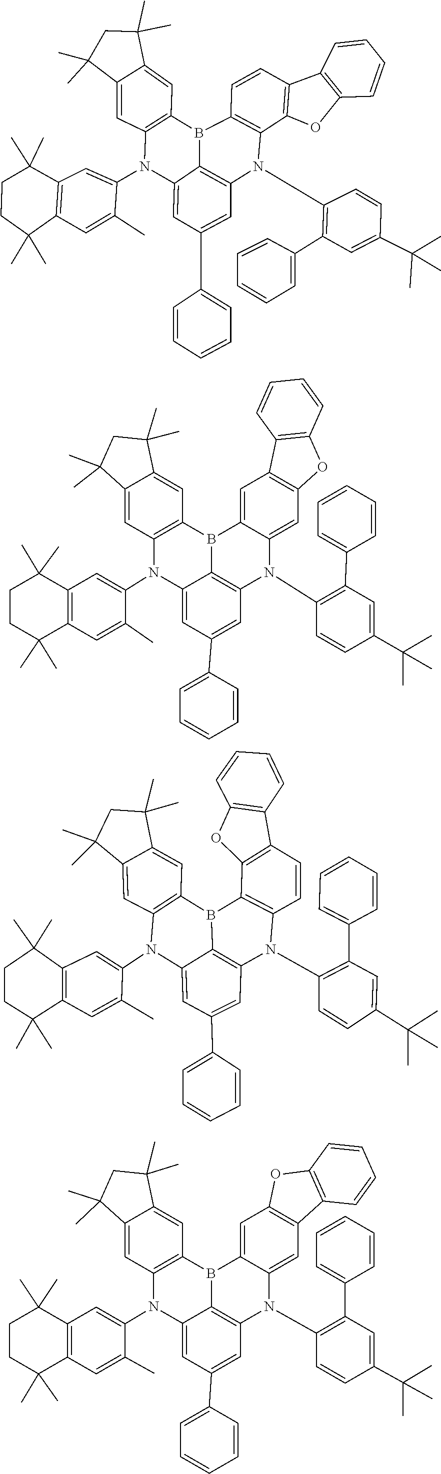

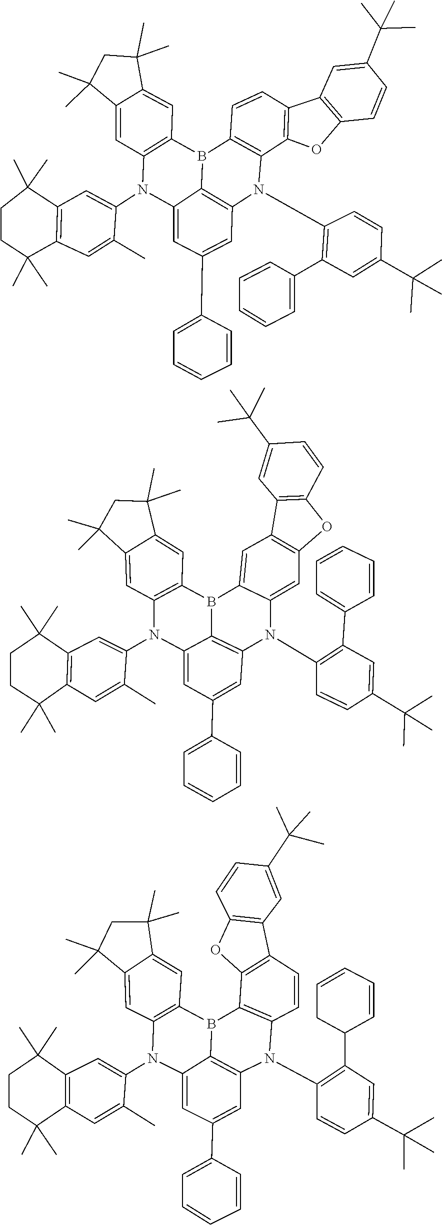

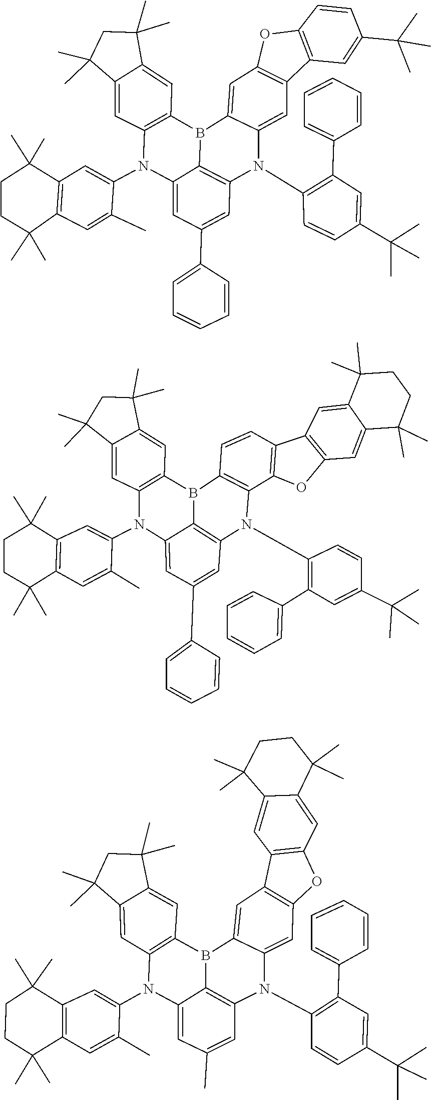 [SMILES: Cc1cc2c(cc1N1c3cc4c(cc3B3c5cc6oc7ccc(C(C)(C)C)cc7c6cc5N(c5ccc(C(C)(C)C)cc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccc(C(C)(C)C)cc5-c5ccccc5)c5cc(-c6ccccc6)cc1c53)C(C)(C)CC4(C)C)C(C)(C)CCC2(C)C ; Cc1cc2c3c(c1)N(c1ccc(C(C)(C)C)cc1-c1ccccc1)c1cc4oc5cc6c(cc5c4cc1B3c1cc3c(cc1N2c1cc2c(cc1C)C(C)(C)CCC2(C)C)C(C)(C)CC3(C)C)C(C)(C)CCC6(C)C]

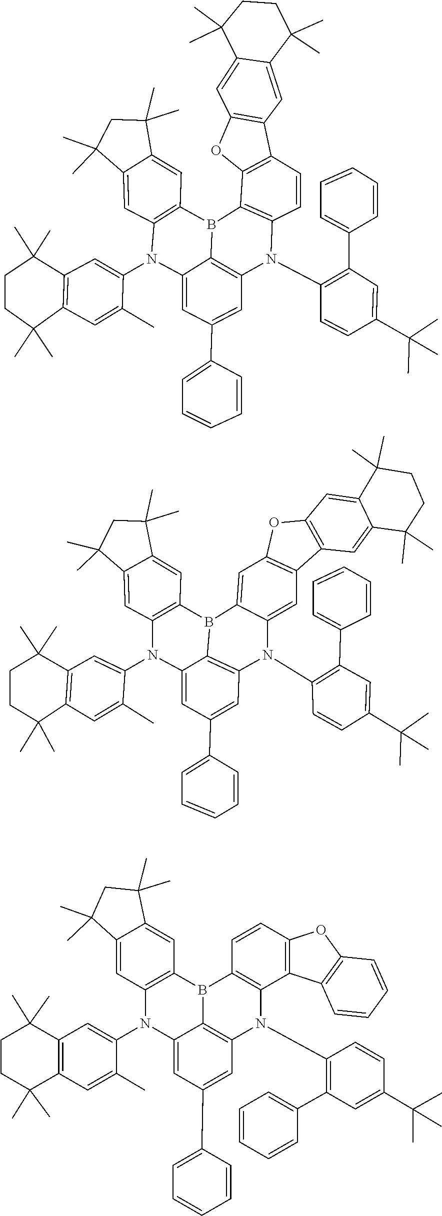 [SMILES: Cc1cc2c(cc1N1c3cc4c(cc3B3c5c1cc(-c1ccccc1)cc5N(c1ccc(C(C)(C)C)cc1-c1ccccc1)c1ccc5c(oc6cc7c(cc65)C(C)(C)CCC7(C)C)c13)C(C)(C)CC4(C)C)C(C)(C)CCC2(C)C ; Cc1cc2c(cc1N1c3cc4c(cc3B3c5cc6oc7cc8c(cc7c6cc5N(c5ccc(C(C)(C)C)cc5-c5ccccc5)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6oc7ccccc7c6c5N(c5ccc(C(C)(C)C)cc5-c5ccccc5)c5cc(-c6ccccc6)cc1c53)C(C)(C)CC4(C)C)C(C)(C)CCC2(C)C]

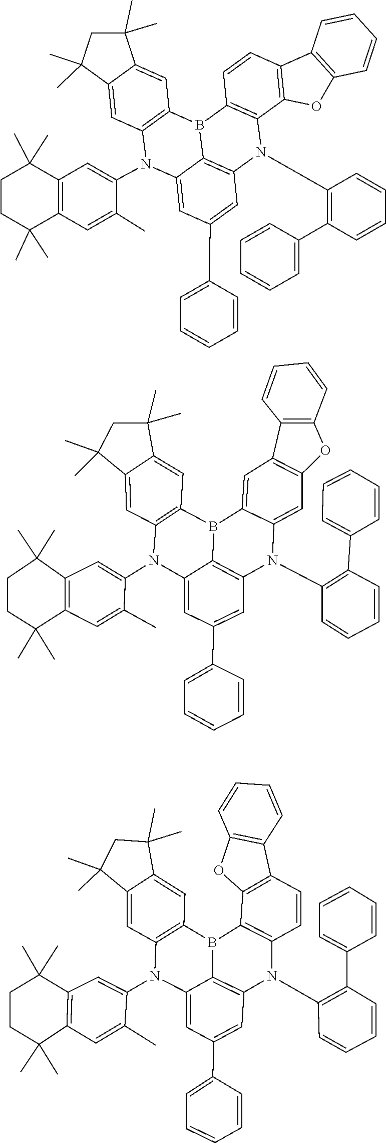 [SMILES: Cc1cc2c(cc1N1c3cc4c(cc3B3c5ccc6c(oc7ccccc76)c5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)oc1ccccc16)C(C)(C)CC4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(oc6ccccc65)c13)C(C)(C)CC4(C)C)C(C)(C)CCC2(C)C]

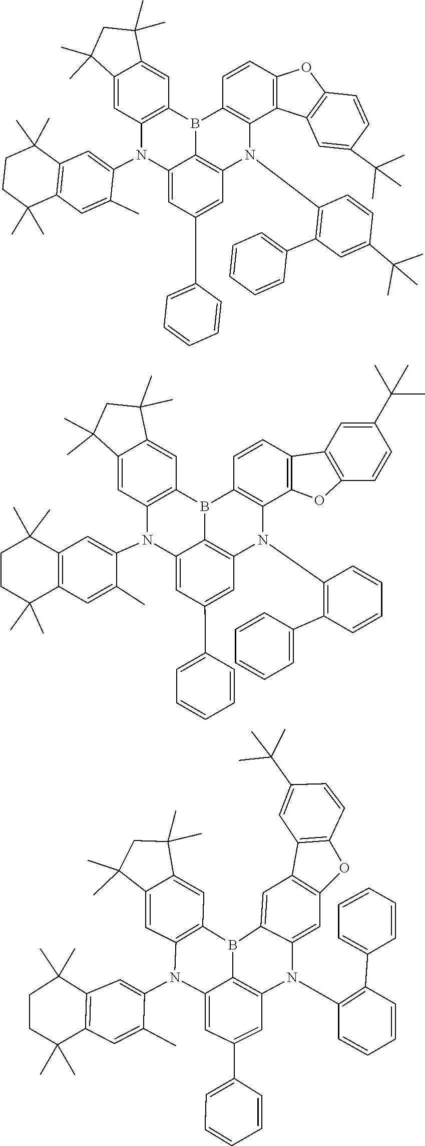

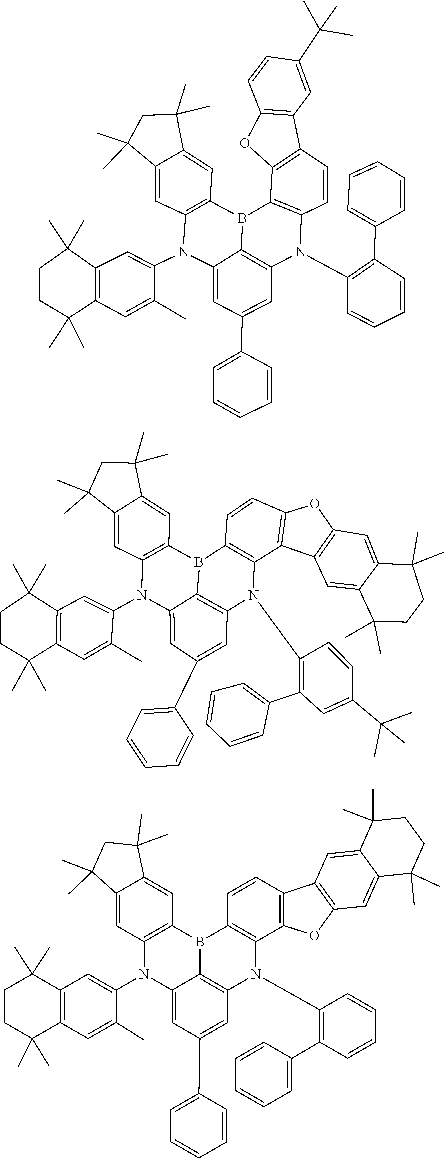

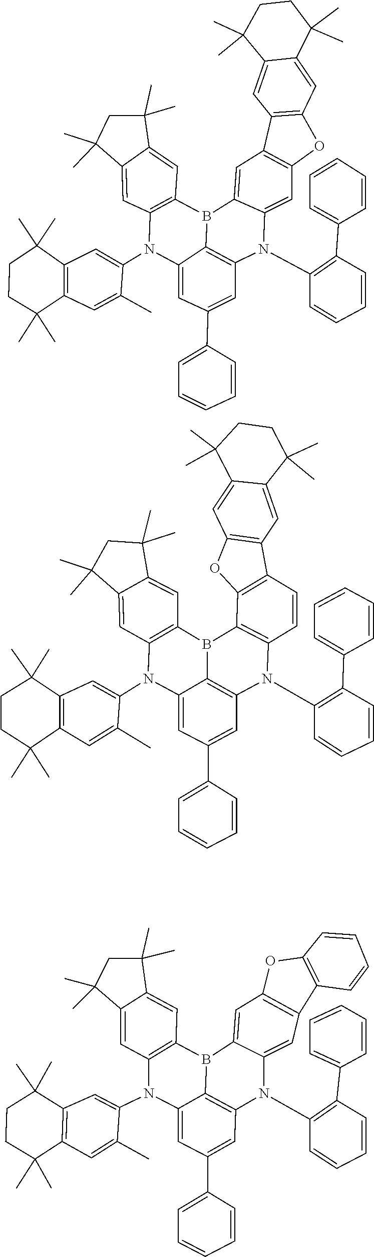

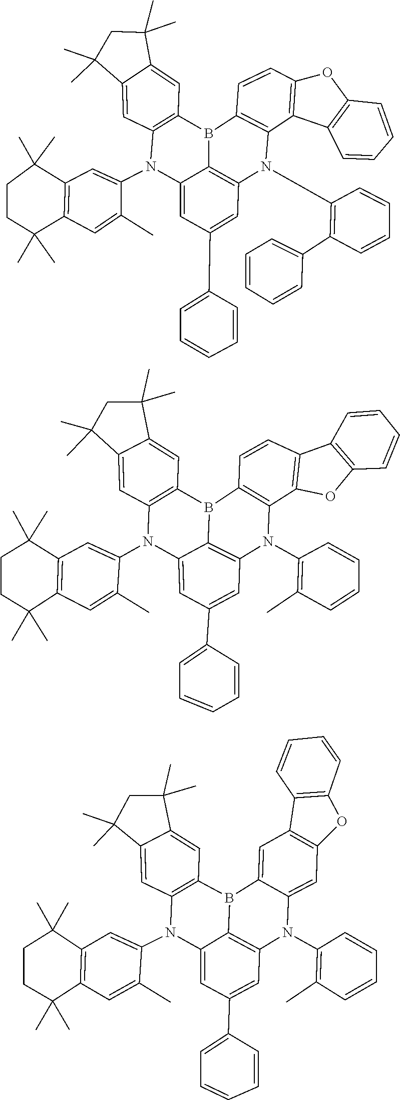

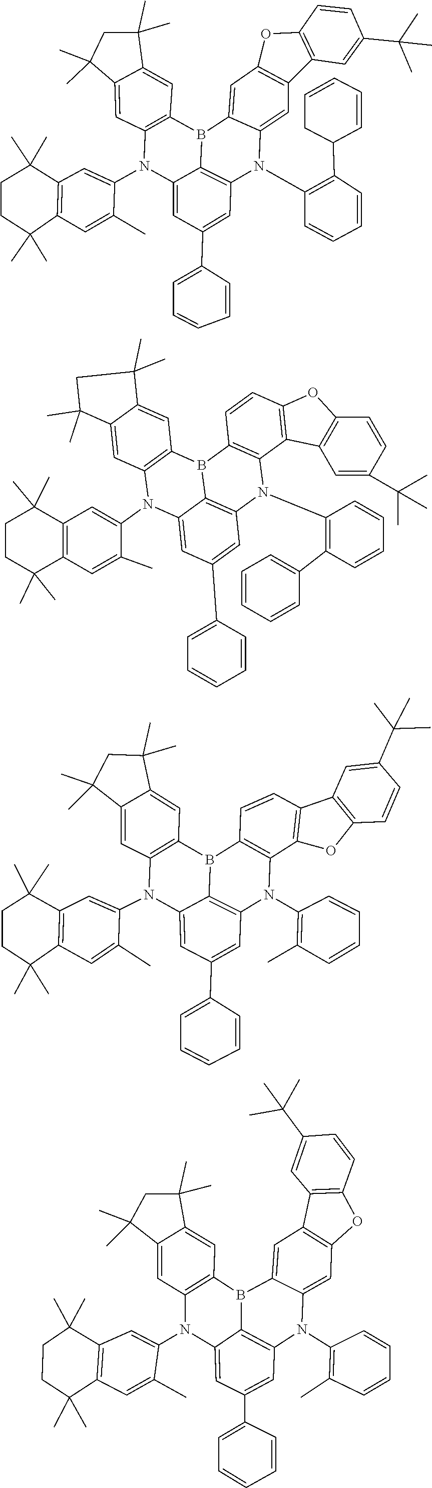

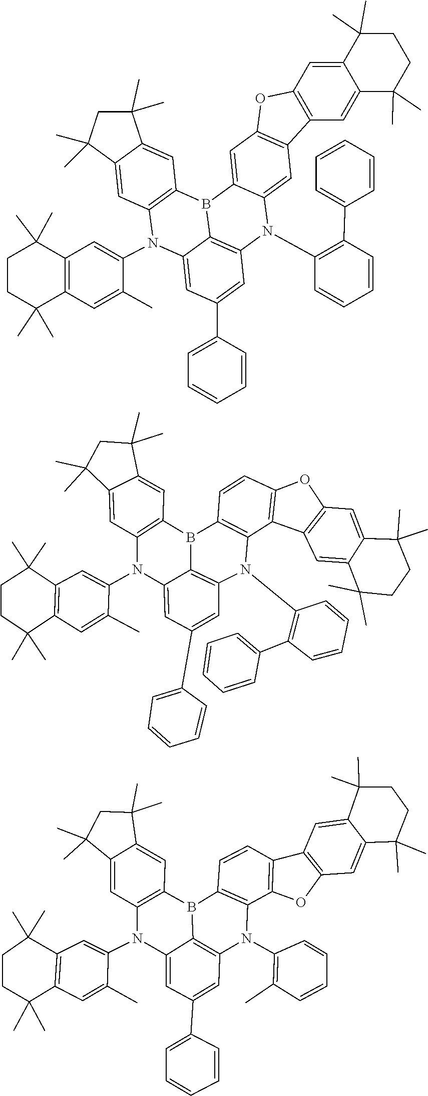 [SMILES: Cc1cc2c(cc1N1c3cc4c(cc3B3c5cc6oc7cc8c(cc7c6cc5N(c5ccccc5-c5ccccc5)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6oc7cc8c(cc7c6c5N(c5ccccc5-c5ccccc5)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5C)c5cc(-c6ccccc6)cc1c53)C(C)(C)CC4(C)C)C(C)(C)CCC2(C)C]

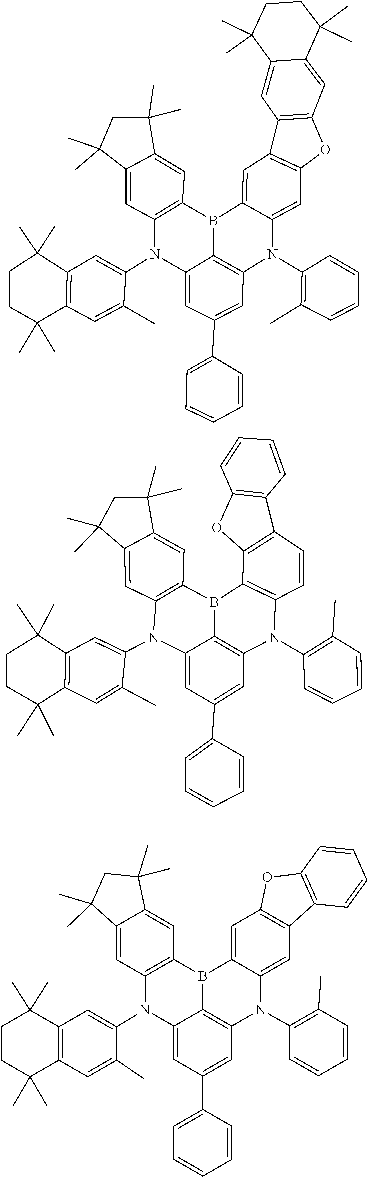

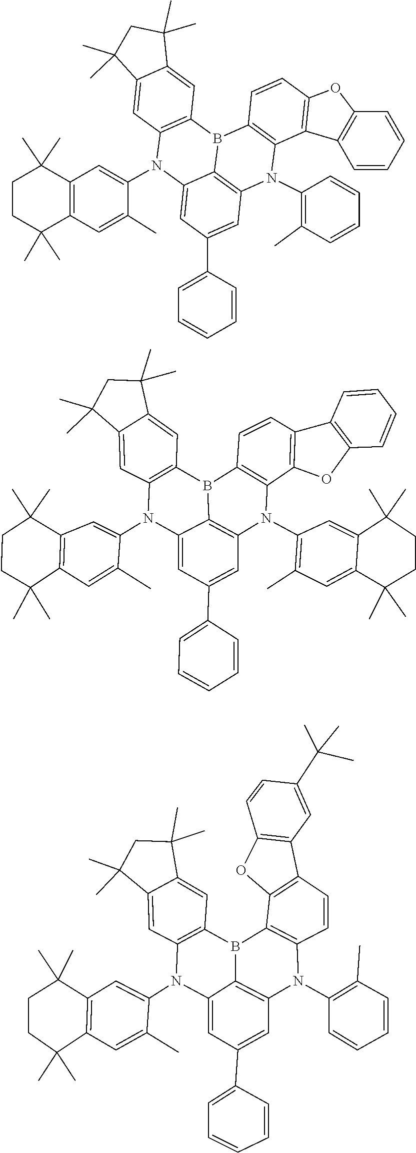

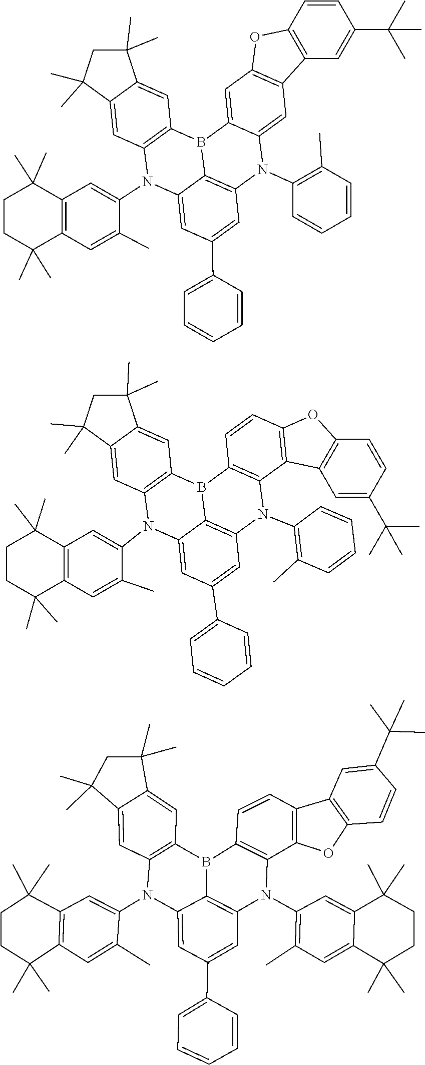 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)oc1ccc(C(C)(C)C)cc13 ; Cc1cc2c(cc1N1c3cc4c(cc3B3c5ccc6oc7ccc(C(C)(C)C)cc7c6c5N(c5ccccc5C)c5cc(-c6ccccc6)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(-c6ccccc6)cc1c53)C(C)(C)CC4(C)C)C(C)(C)CCC2(C)C]

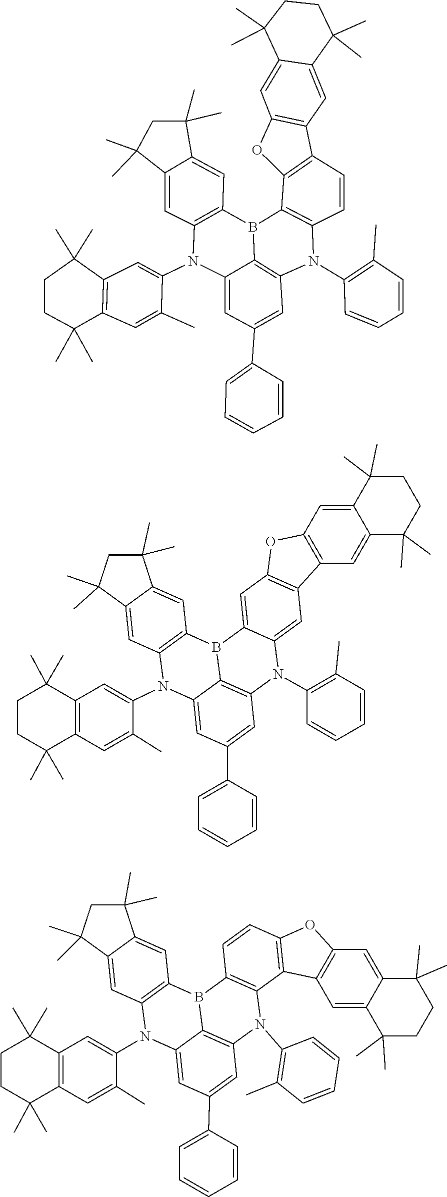 [SMILES: Cc1cc2c(cc1N1c3cc4c(cc3B3c5c1cc(-c1ccccc1)cc5N(c1ccccc1C)c1ccc5c(oc6cc7c(cc65)C(C)(C)CCC7(C)C)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)oc1cc2c(cc13)C(C)(C)CCC2(C)C ; Cc1cc2c(cc1N1c3cc4c(cc3B3c5ccc6oc7cc8c(cc7c6c5N(c5ccccc5C)c5cc(-c6ccccc6)cc1c53)C(C)(C)CCC8(C)C)C(C)(C)CC4(C)C)C(C)(C)CCC2(C)C]

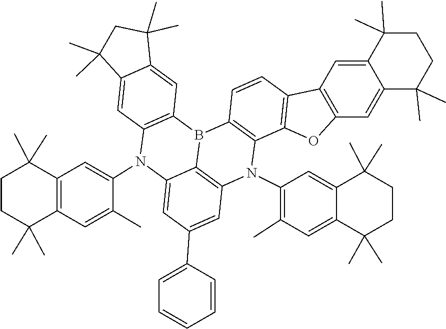 [SMILES: Cc1cc2c(cc1N1c3cc4c(cc3B3c5ccc6c(oc7cc8c(cc76)C(C)(C)CCC8(C)C)c5N(c5cc6c(cc5C)C(C)(C)CCC6(C)C)c5cc(-c6ccccc6)cc1c53)C(C)(C)CC4(C)C)C(C)(C)CCC2(C)C]

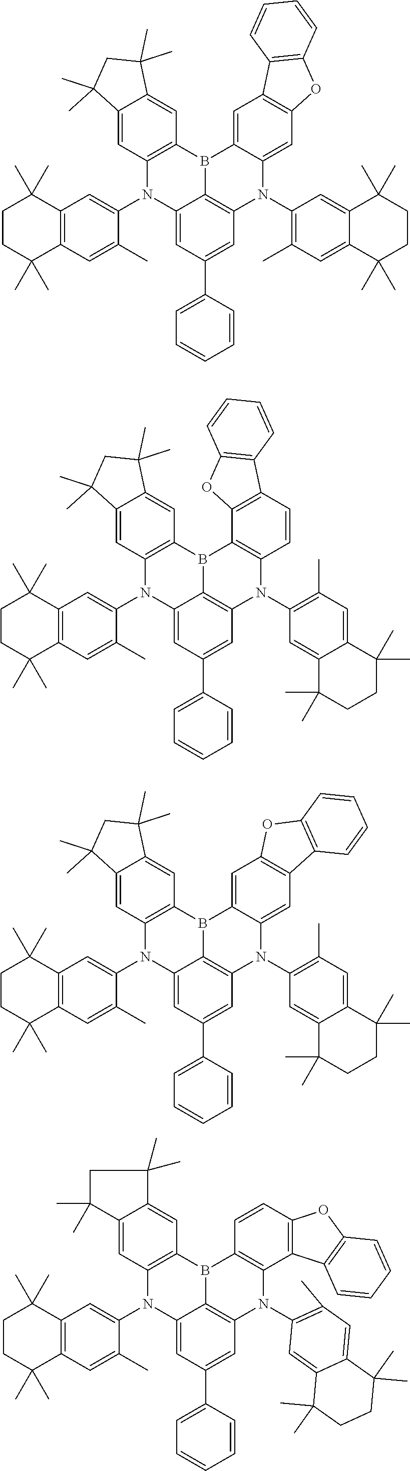

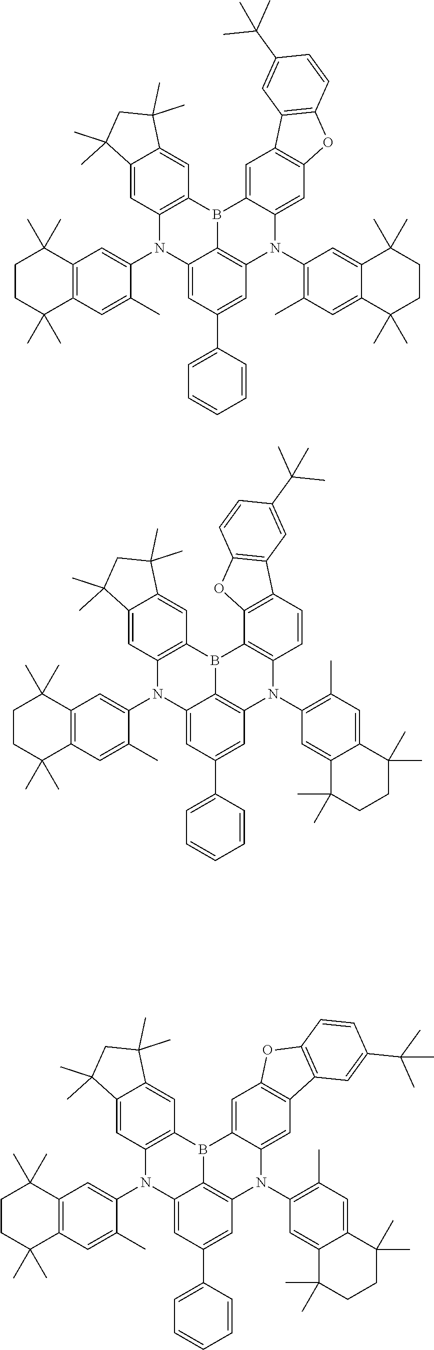 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(oc6ccc(C(C)(C)C)cc65)c13)C(C)(C)CC4(C)C)C(C)(C)CCC2(C)C ; Cc1cc2c(cc1N1c3cc4c(cc3B3c5cc6oc7ccc(C(C)(C)C)cc7c6cc5N(c5cc6c(cc5C)C(C)(C)CCC6(C)C)c5cc(-c6ccccc6)cc1c53)C(C)(C)CC4(C)C)C(C)(C)CCC2(C)C]

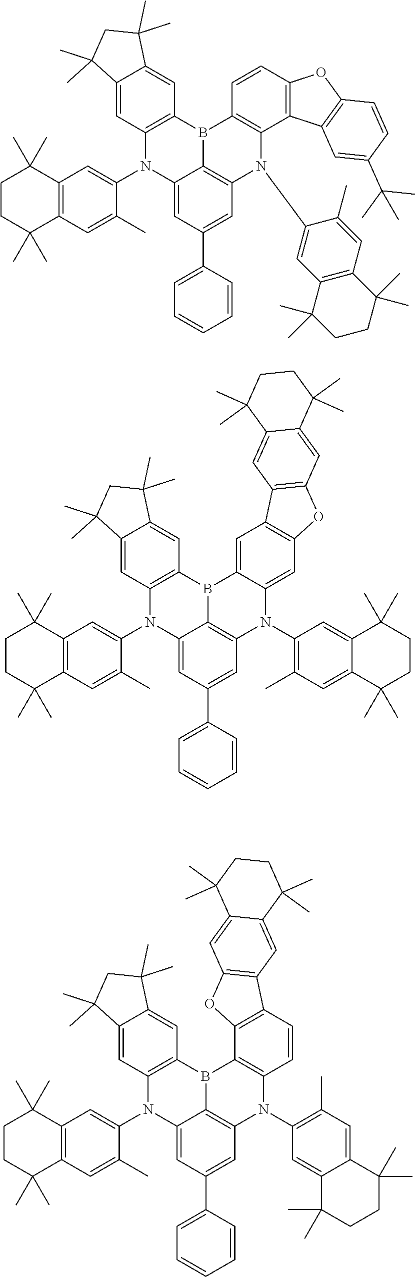

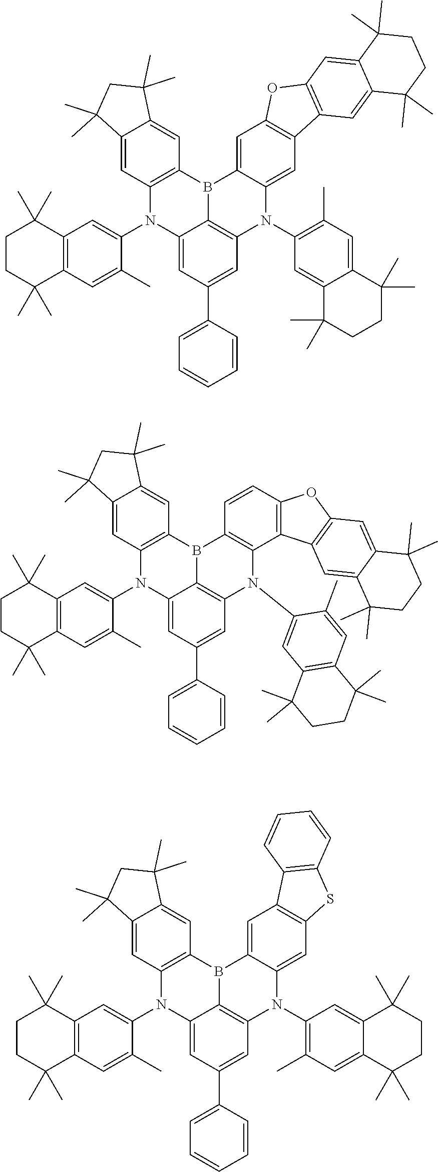 [SMILES: Cc1cc2c(cc1N1c3cc4c(cc3B3c5cc6oc7cc8c(cc7c6cc5N(c5cc6c(cc5C)C(C)(C)CCC6(C)C)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6oc7cc8c(cc7c6c5N(c5cc6c(cc5C)C(C)(C)CCC6(C)C)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)sc1ccccc16)C(C)(C)CC4(C)C)C(C)(C)CCC2(C)C]

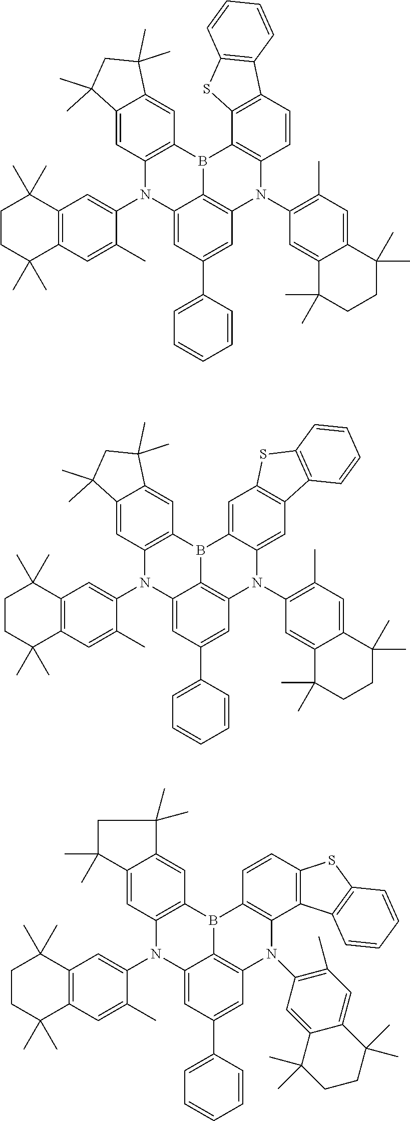 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(sc6ccccc65)c13)C(C)(C)CC4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(-c6ccccc6)cc1c53)C(C)(C)CC4(C)C)C(C)(C)CCC2(C)C ; Cc1cc2c(cc1N1c3cc4c(cc3B3c5ccc6sc7ccccc7c6c5N(c5cc6c(cc5C)C(C)(C)CCC6(C)C)c5cc(-c6ccccc6)cc1c53)C(C)(C)CC4(C)C)C(C)(C)CCC2(C)C]

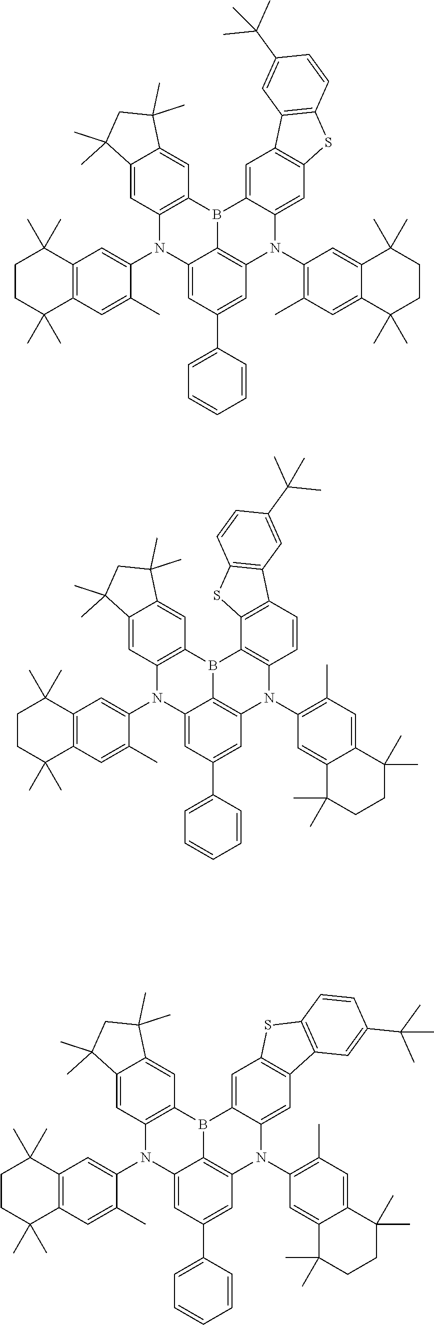 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5cc6sc7ccc(C(C)(C)C)cc7c6cc5N(c5cc6c(cc5C)C(C)(C)CCC6(C)C)c5cc(-c6ccccc6)cc1c53)C(C)(C)CC4(C)C)C(C)(C)CCC2(C)C]

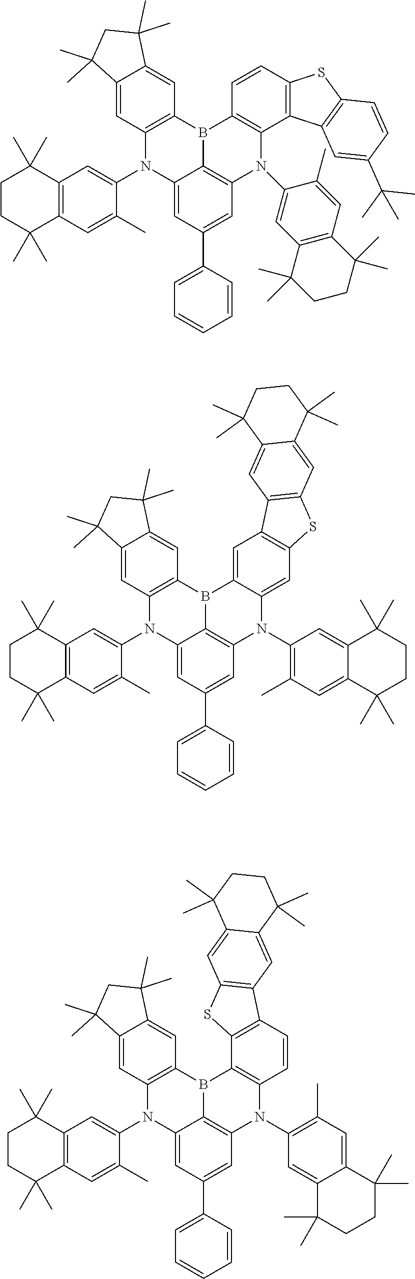 [SMILES: Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(-c6ccccc6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)sc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(sc6cc7c(cc65)C(C)(C)CCC7(C)C)c13)C(C)(C)CC4(C)C)C(C)(C)CCC2(C)C]

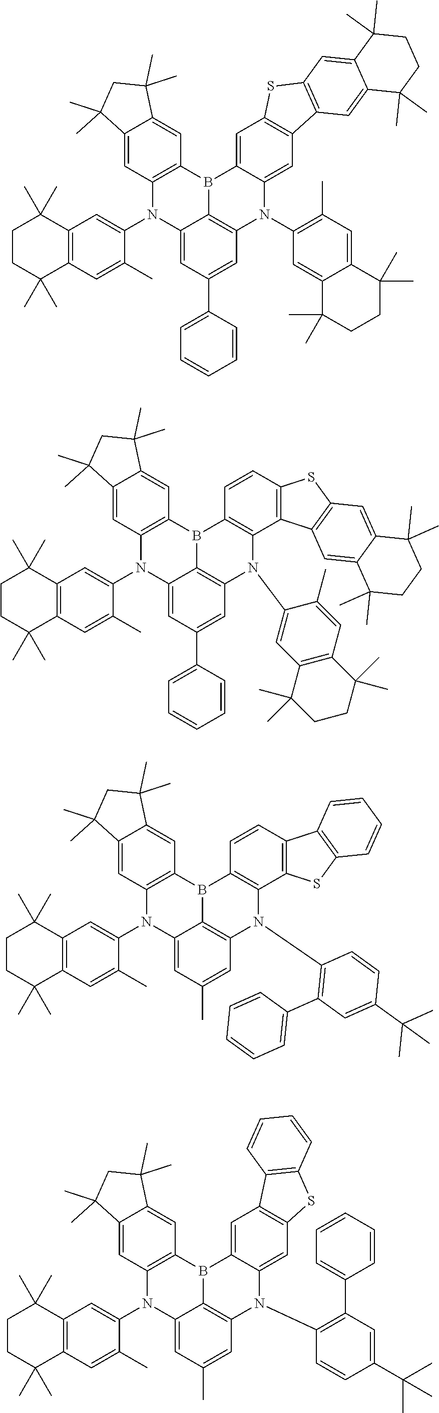

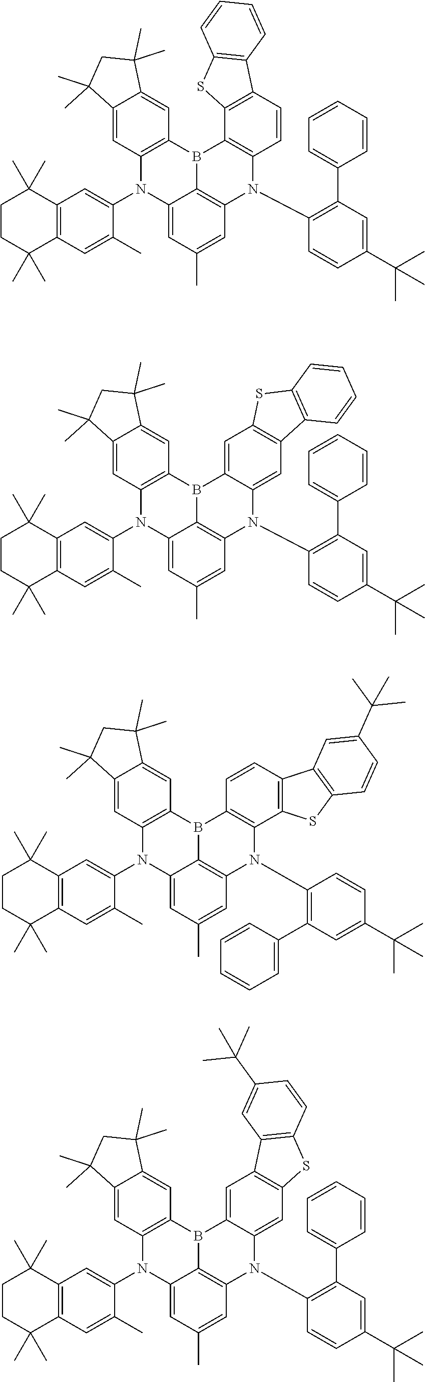

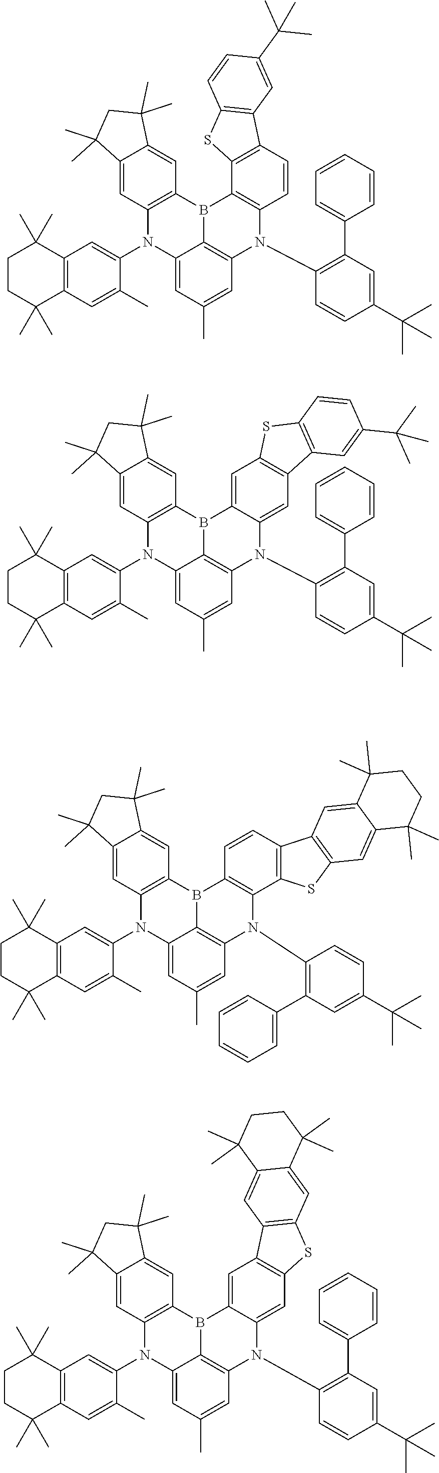

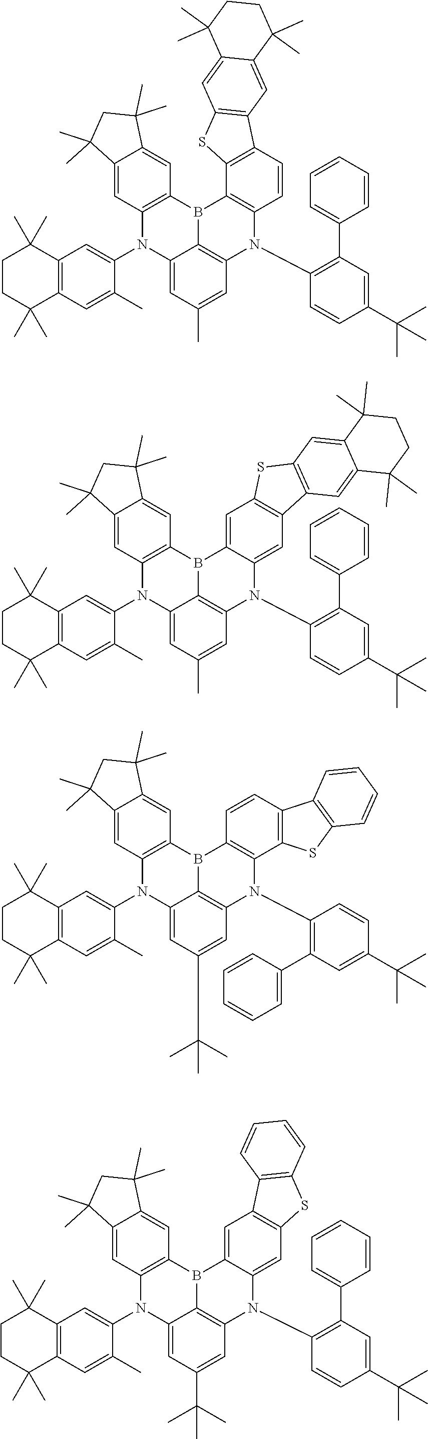

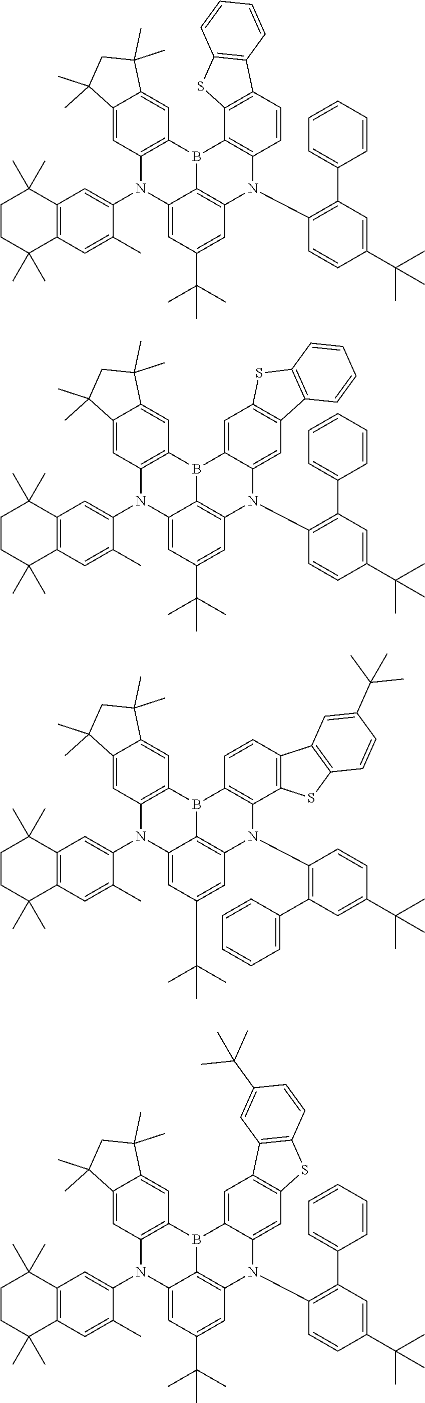

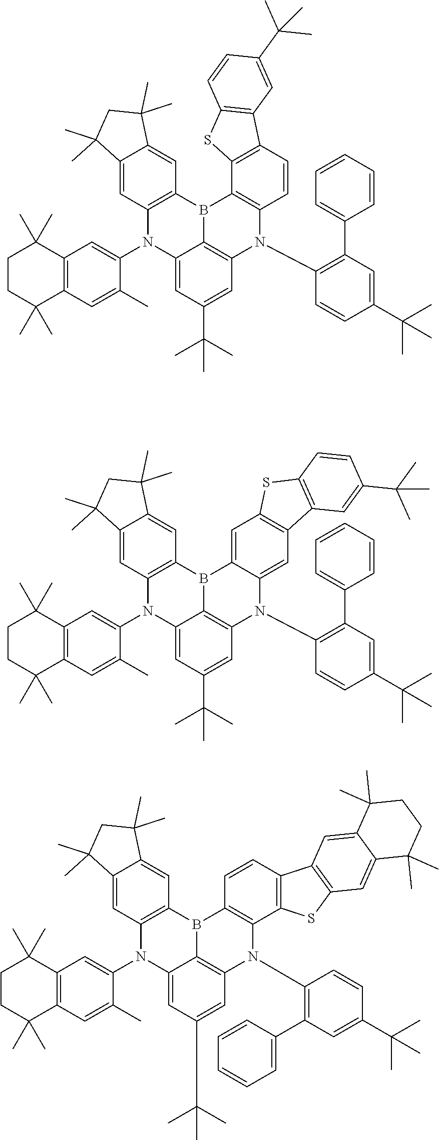 [SMILES: Cc1cc2c(cc1N1c3cc4c(cc3B3c5c1cc(C(C)(C)C)cc5N(c1ccc(C(C)(C)C)cc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(C(C)(C)C)cc1c53)C(C)(C)CC4(C)C)C(C)(C)CCC2(C)C]

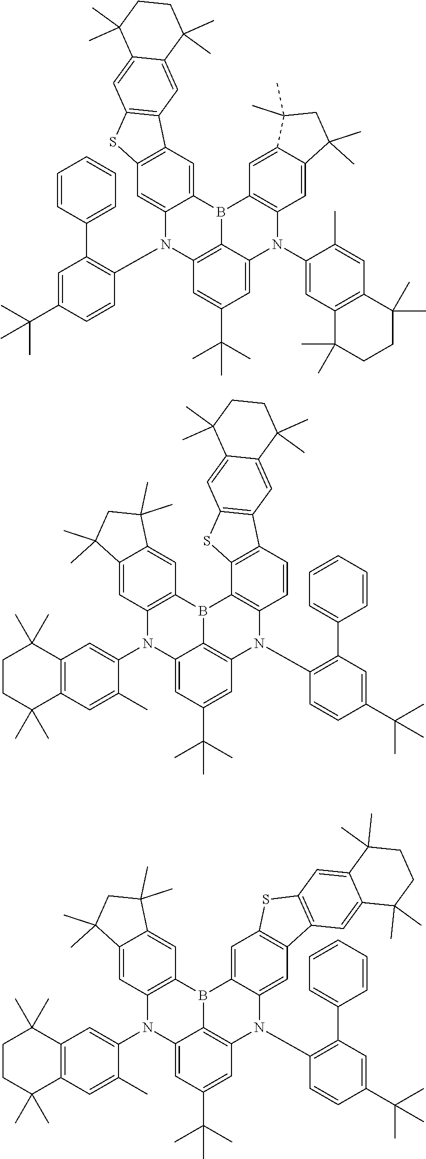

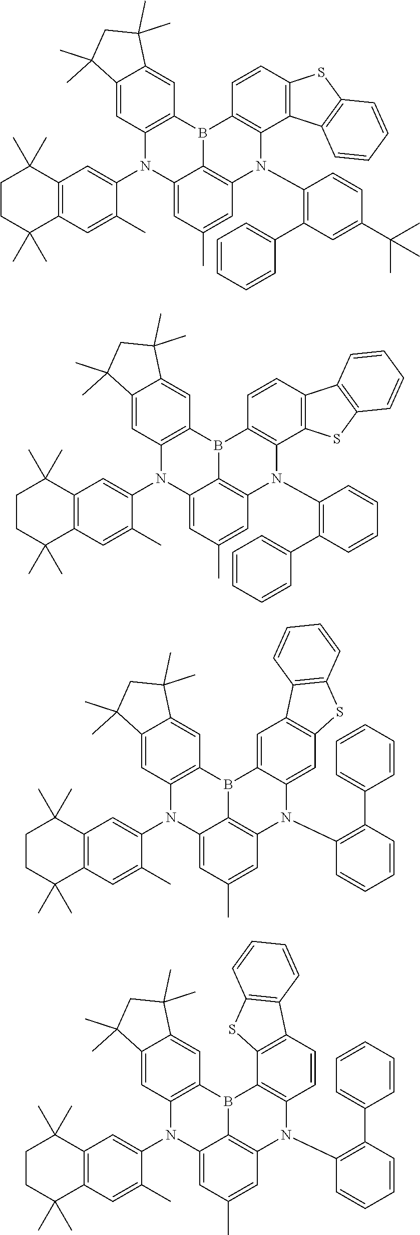

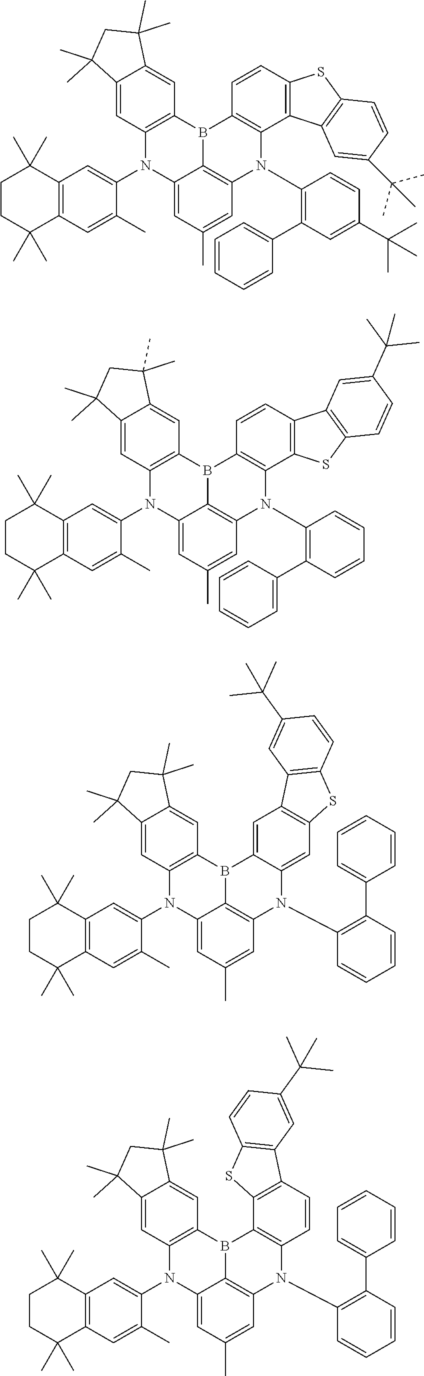

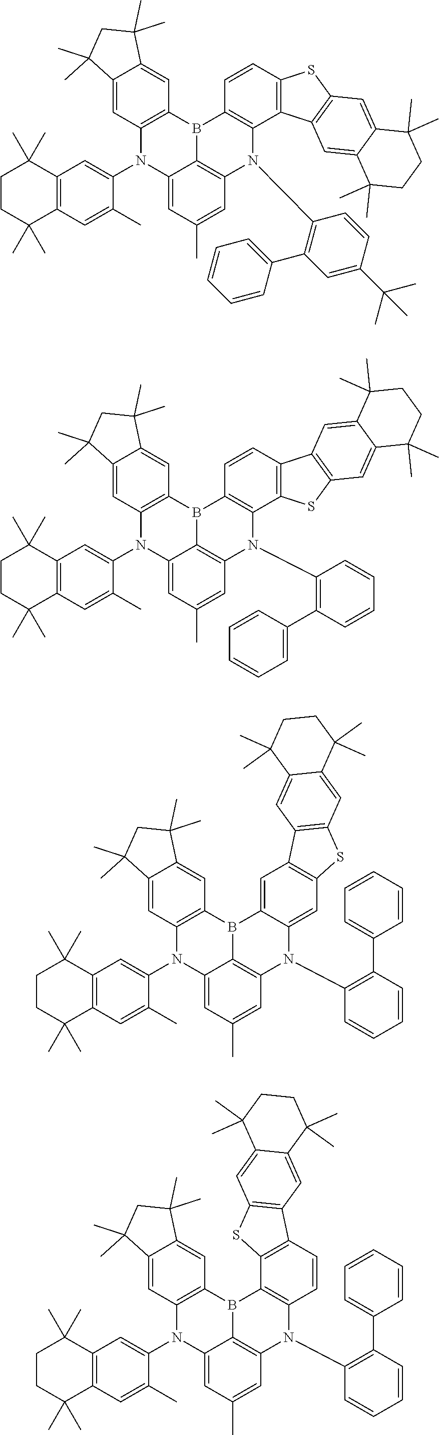

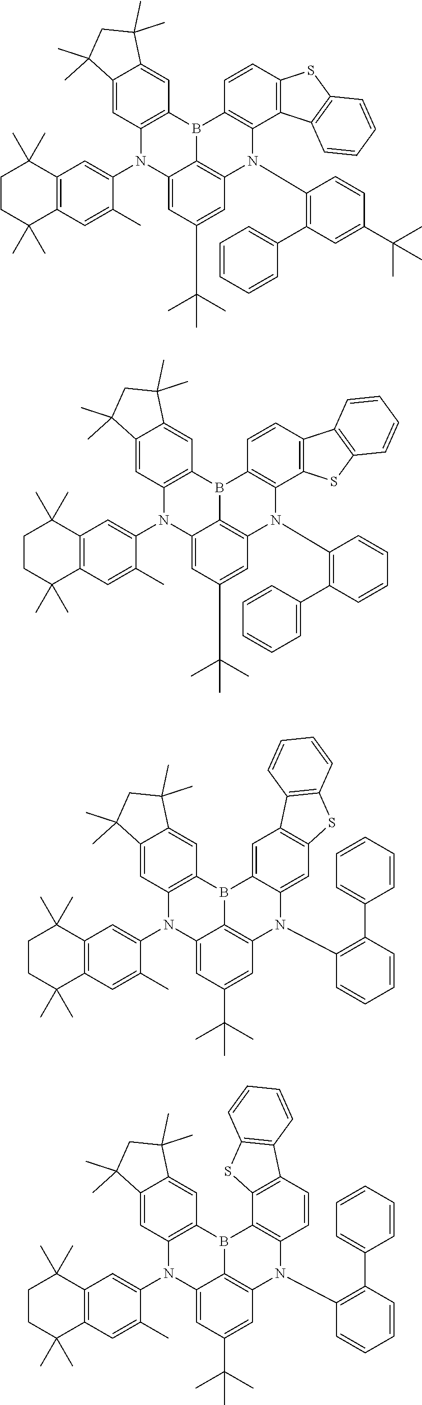

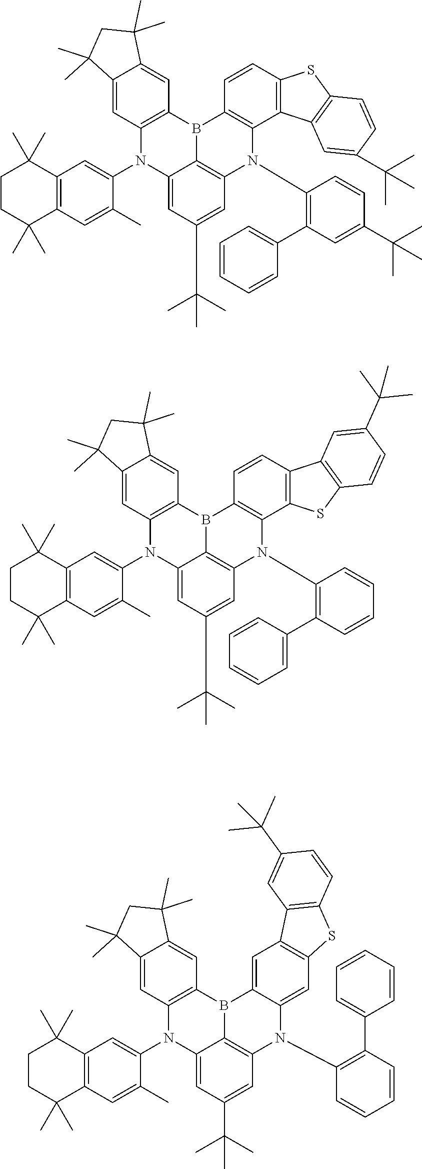 [SMILES: Cc1cc2c(cc1N1c3cc4c(cc3B3c5ccc6sc7ccc(C(C)(C)C)cc7c6c5N(c5ccc(C(C)(C)C)cc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)sc1ccc(C(C)(C)C)cc16)C(C)(C)CC4(C)C)C(C)(C)CCC2(C)C]

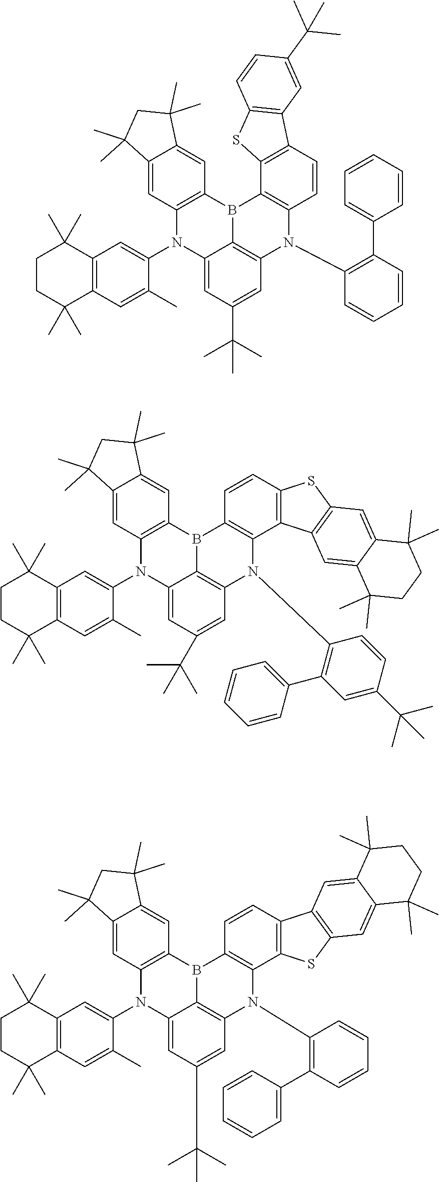 [SMILES: Cc1cc2c(cc1N1c3cc4c(cc3B3c5c1cc(C(C)(C)C)cc5N(c1ccccc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(C(C)(C)C)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5-c5ccccc5)c5cc(C(C)(C)C)cc1c53)C(C)(C)CC4(C)C)C(C)(C)CCC2(C)C]

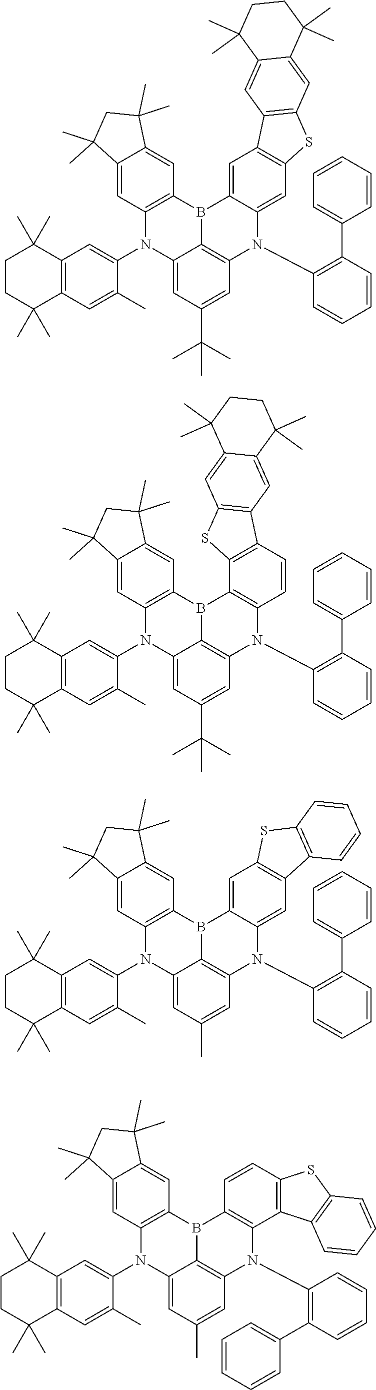

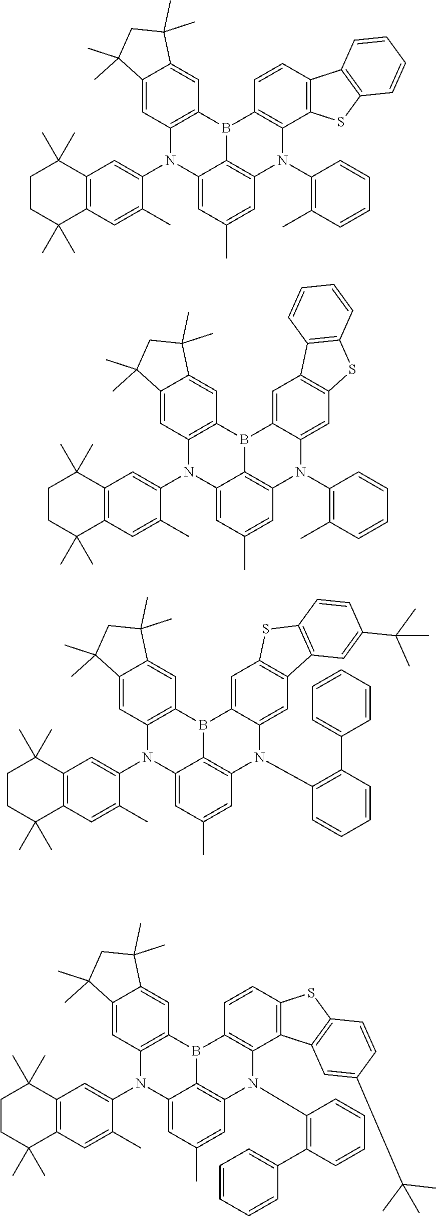 [SMILES: Cc1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)CC3(C)C ; Cc1cc2c3c(c1)N(c1ccccc1C)c1cc4sc5ccccc5c4cc1B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1ccc(C(C)(C)C)cc14 ; Cc1cc2c3c(c1)N(c1ccccc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)CC3(C)C]

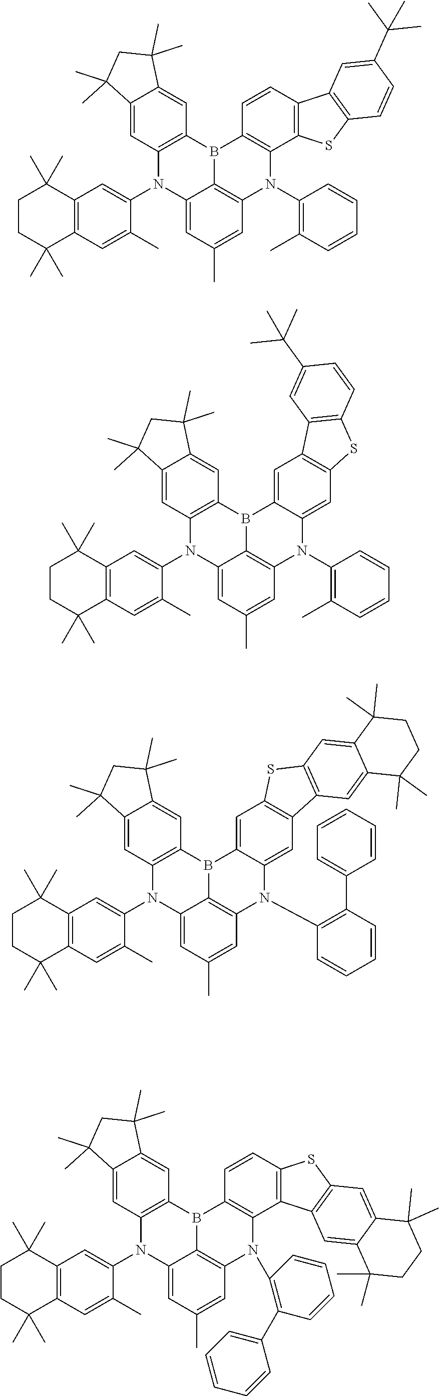 [SMILES: Cc1cc2c3c(c1)N(c1ccccc1C)c1c(ccc4c1sc1ccc(C(C)(C)C)cc14)B3c1cc3c(cc1N2c1cc2c(cc1C)C(C)(C)CCC2(C)C)C(C)(C)CC3(C)C ; Cc1cc2c3c(c1)N(c1ccccc1C)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C ; Cc1cc2c3c(c1)N(c1ccccc1-c1ccccc1)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C]

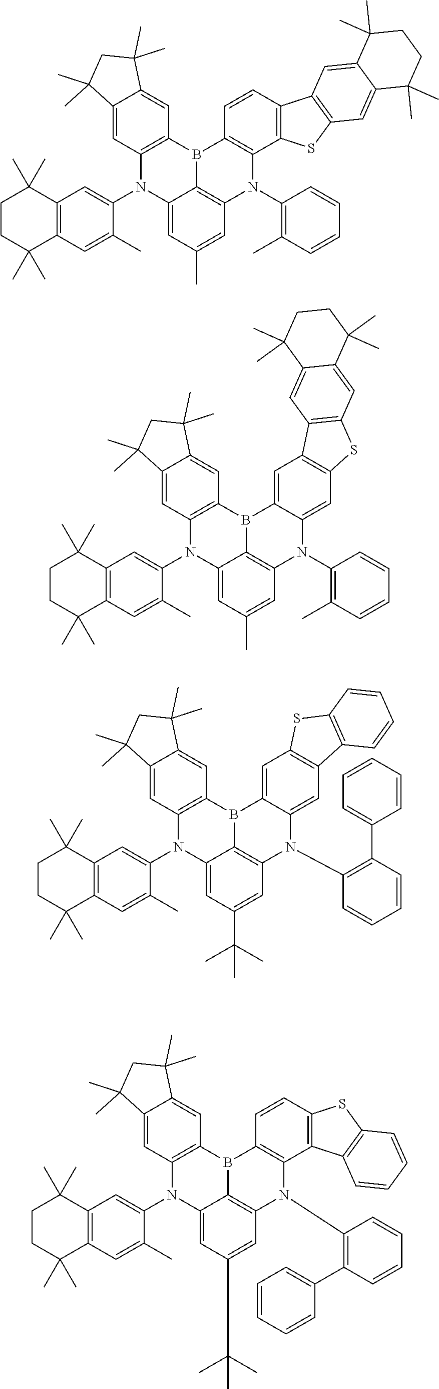 [SMILES: Cc1cc2c3c(c1)N(c1ccccc1C)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C ; Cc1cc2c3c(c1)N(c1ccccc1C)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1cc2c(cc1N1c3cc4c(cc3B3c5cc6sc7ccccc7c6cc5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(C(C)(C)C)cc1c53)C(C)(C)CC4(C)C)C(C)(C)CCC2(C)C]

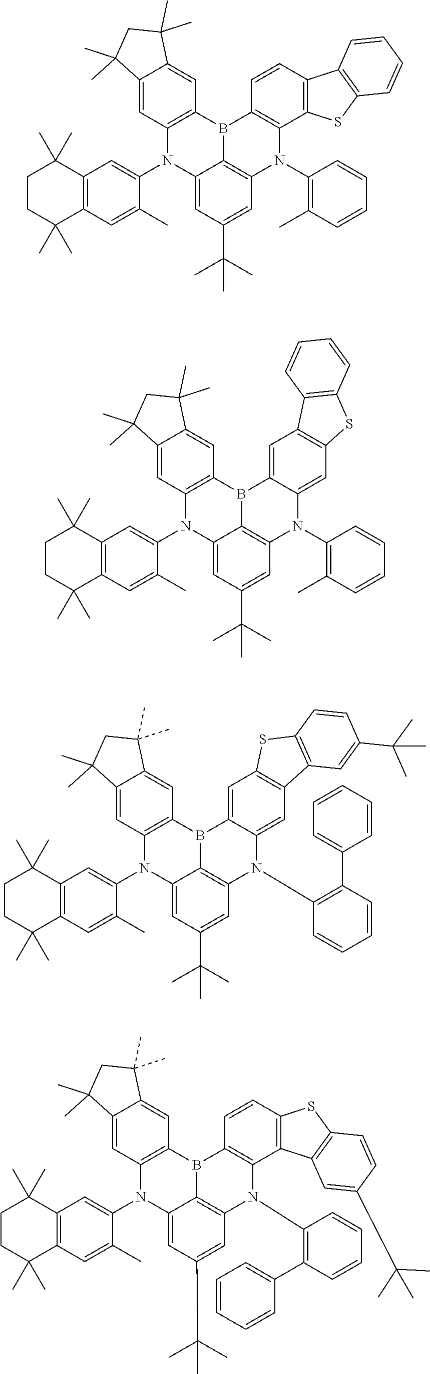

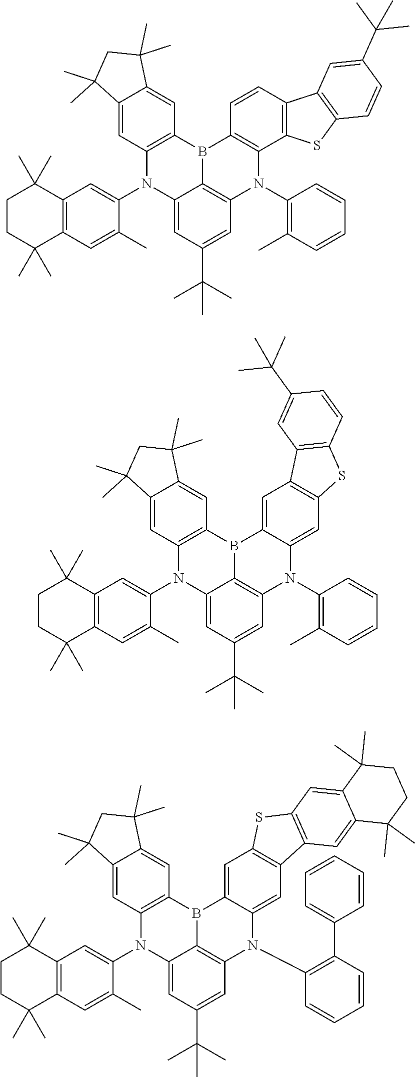 [SMILES: Cc1cc2c(cc1N1c3cc4c(cc3B3c5ccc6c(sc7ccc(C(C)(C)C)cc76)c5N(c5ccccc5C)c5cc(C(C)(C)C)cc1c53)C(C)(C)CC4(C)C)C(C)(C)CCC2(C)C ; Cc1ccccc1N1c2cc3sc4ccc(C(C)(C)C)cc4c3cc2B2c3cc4c(cc3N(c3cc5c(cc3C)C(C)(C)CCC5(C)C)c3cc(C(C)(C)C)cc1c32)C(C)(C)CC4(C)C ; Cc1cc2c(cc1N1c3cc4c(cc3B3c5cc6sc7cc8c(cc7c6cc5N(c5ccccc5-c5ccccc5)c5cc(C(C)(C)C)cc1c53)C(C)(C)CCC8(C)C)C(C)(C)CC4(C)C)C(C)(C)CCC2(C)C]

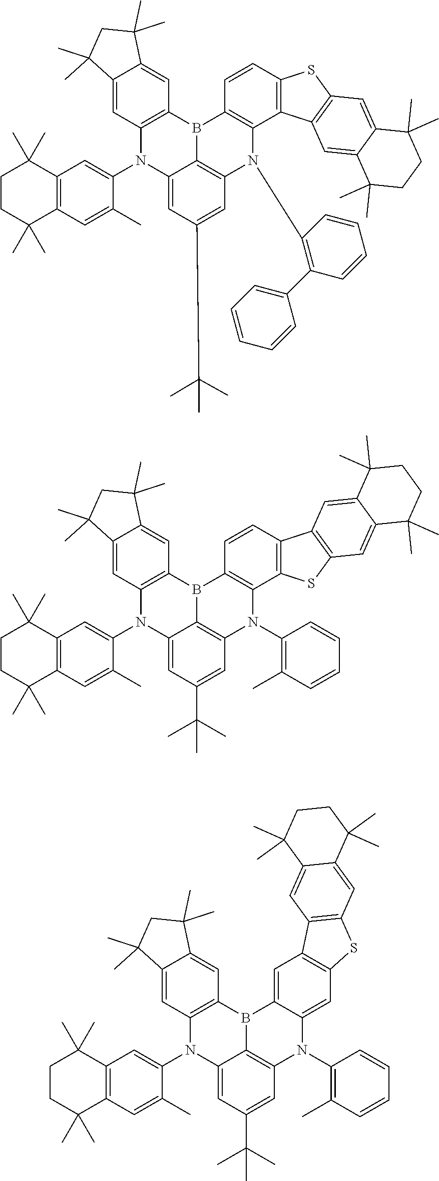 [SMILES: Cc1cc2c(cc1N1c3cc4c(cc3B3c5ccc6sc7cc8c(cc7c6c5N(c5ccccc5-c5ccccc5)c5cc(C(C)(C)C)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(C(C)(C)C)cc1c53)C(C)(C)CC4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(C(C)(C)C)cc1c32)C(C)(C)CC4(C)C)C(C)(C)CCC5(C)C]

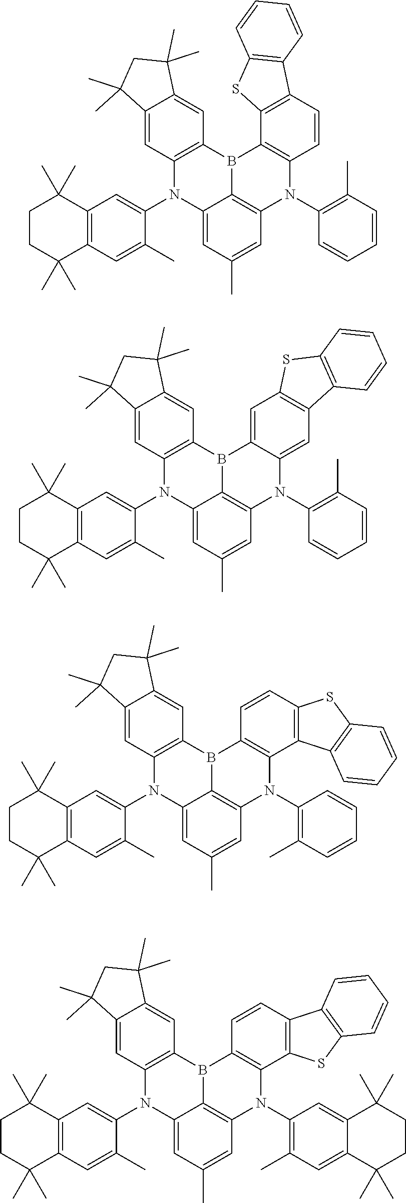 [SMILES: Cc1cc2c3c(c1)N(c1ccccc1C)c1ccc4c(sc5ccccc54)c1B3c1cc3c(cc1N2c1cc2c(cc1C)C(C)(C)CCC2(C)C)C(C)(C)CC3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1ccccc14 ; Cc1cc2c3c(c1)N(c1ccccc1C)c1c(ccc4sc5ccccc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1sc1ccccc14)B3c1cc3c(cc1N2c1cc2c(cc1C)C(C)(C)CCC2(C)C)C(C)(C)CC3(C)C]

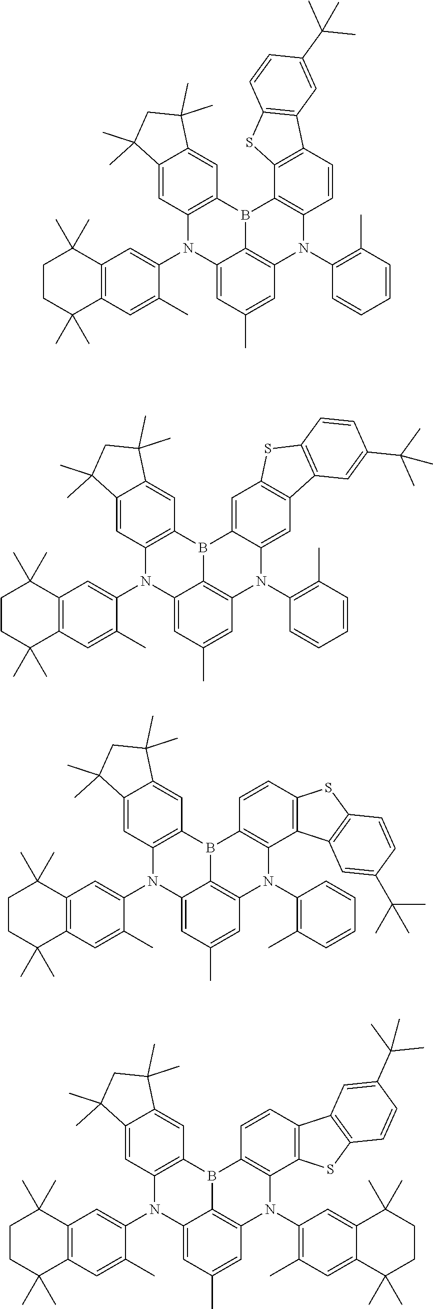 [SMILES: Cc1cc2c3c(c1)N(c1ccccc1C)c1ccc4c(sc5ccc(C(C)(C)C)cc54)c1B3c1cc3c(cc1N2c1cc2c(cc1C)C(C)(C)CCC2(C)C)C(C)(C)CC3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1ccc(C(C)(C)C)cc14 ; Cc1cc2c3c(c1)N(c1ccccc1C)c1c(ccc4sc5ccc(C(C)(C)C)cc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1sc1ccc(C(C)(C)C)cc14)B3c1cc3c(cc1N2c1cc2c(cc1C)C(C)(C)CCC2(C)C)C(C)(C)CC3(C)C]

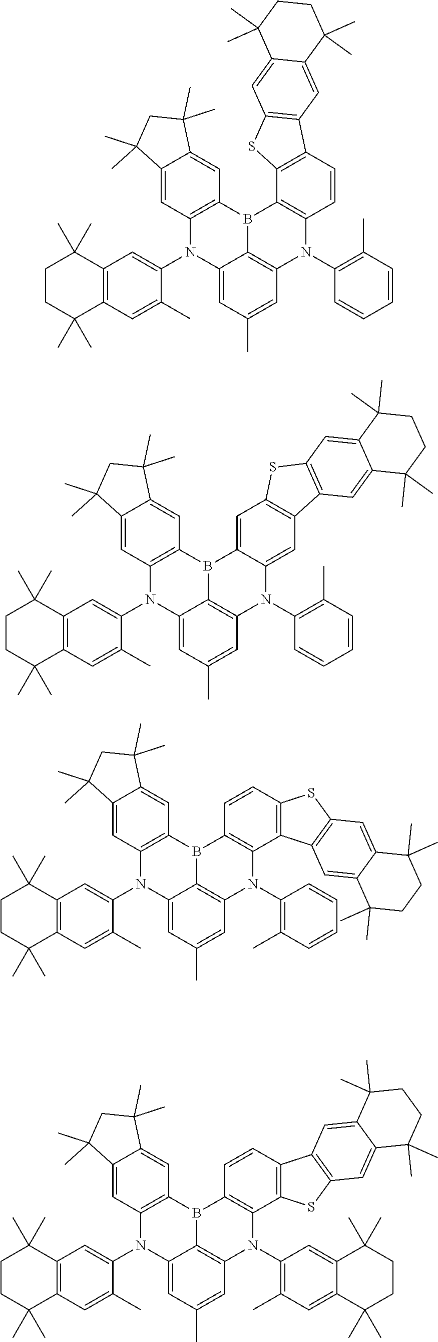

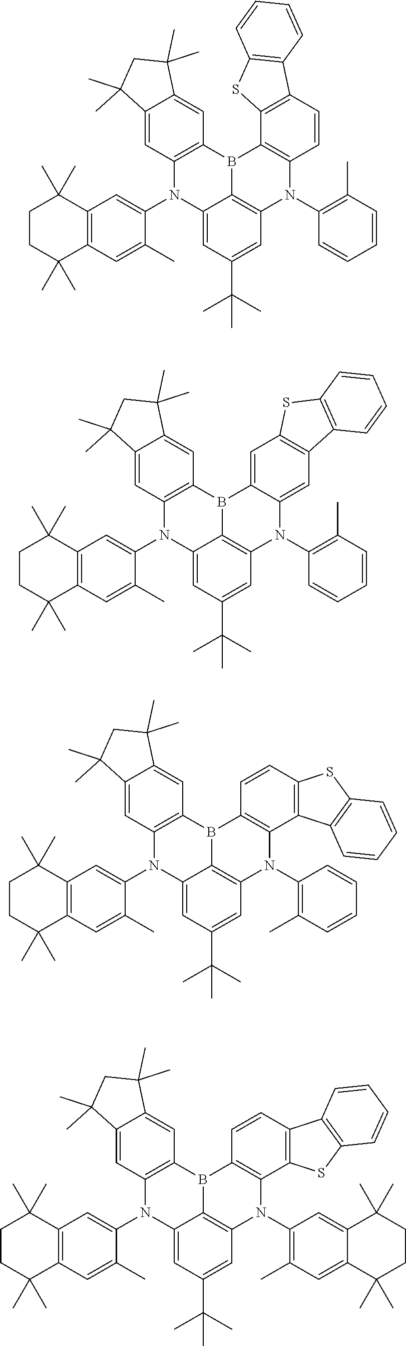 [SMILES: Cc1cc2c(cc1N1c3cc4c(cc3B3c5c1cc(C(C)(C)C)cc5N(c1ccccc1C)c1ccc5c(sc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)sc1ccccc13 ; Cc1cc2c(cc1N1c3cc4c(cc3B3c5ccc6sc7ccccc7c6c5N(c5ccccc5C)c5cc(C(C)(C)C)cc1c53)C(C)(C)CC4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(C(C)(C)C)cc1c53)C(C)(C)CC4(C)C)C(C)(C)CCC2(C)C]

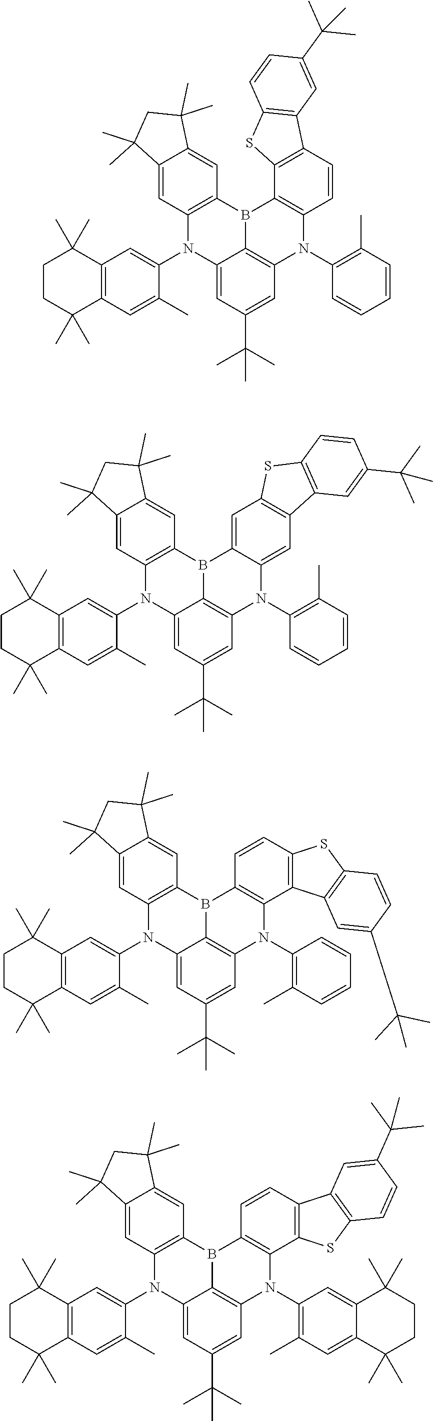

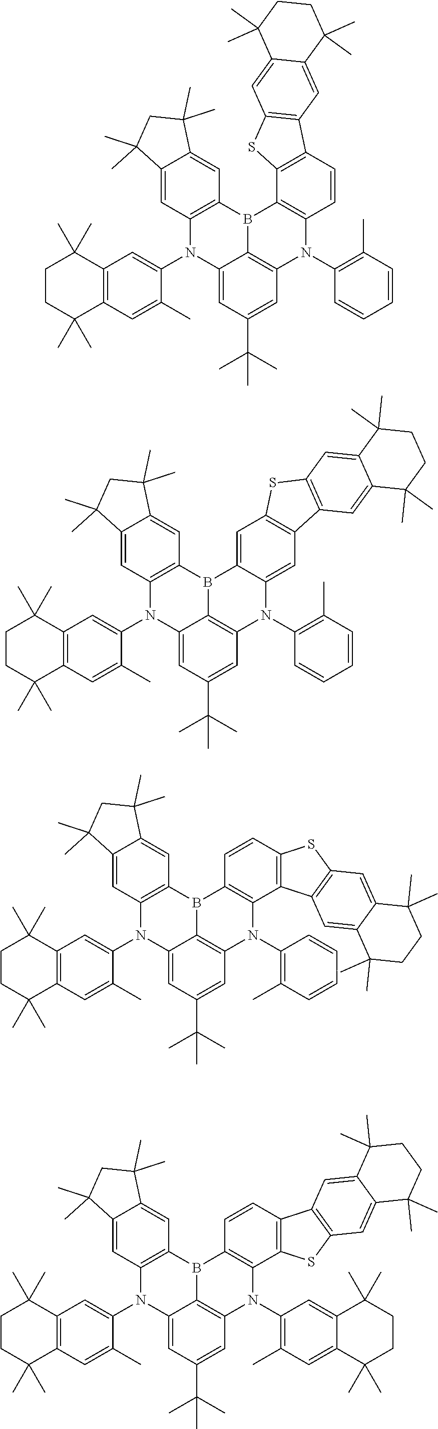

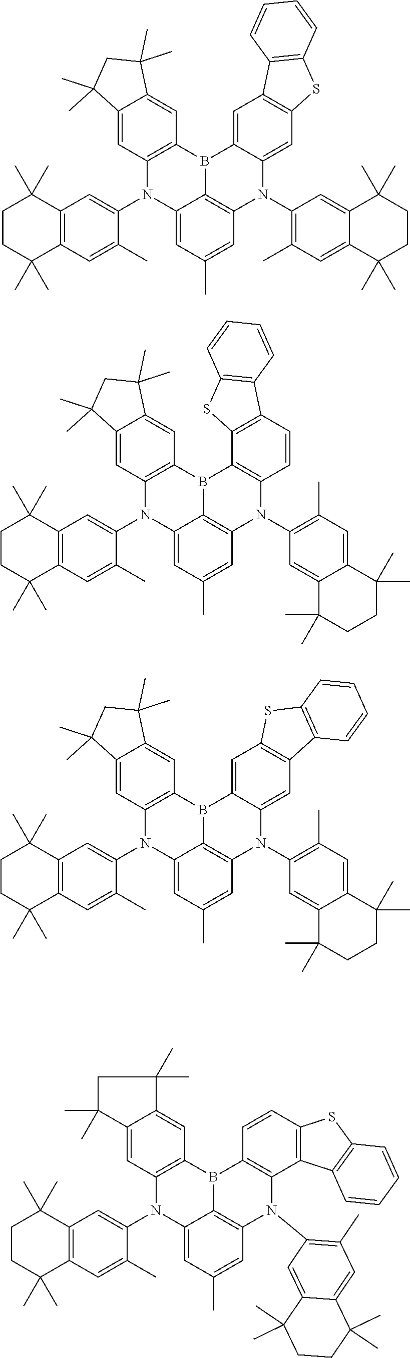

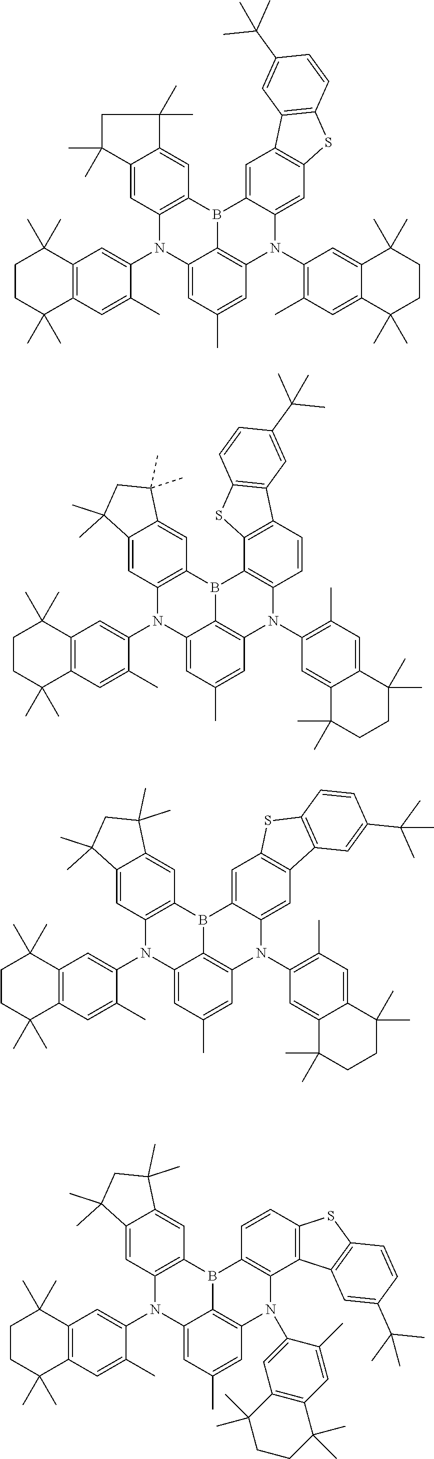

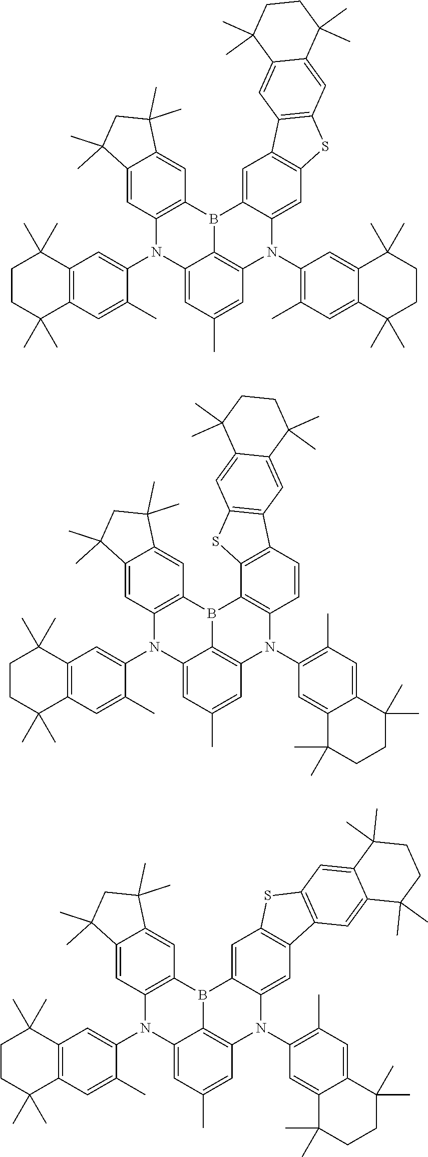 [SMILES: Cc1cc2c3c(c1)N(c1cc4c(cc1C)C(C)(C)CCC4(C)C)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1cc2c3c(c1)N(c1cc4c(cc1C)C(C)(C)CCC4(C)C)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C]

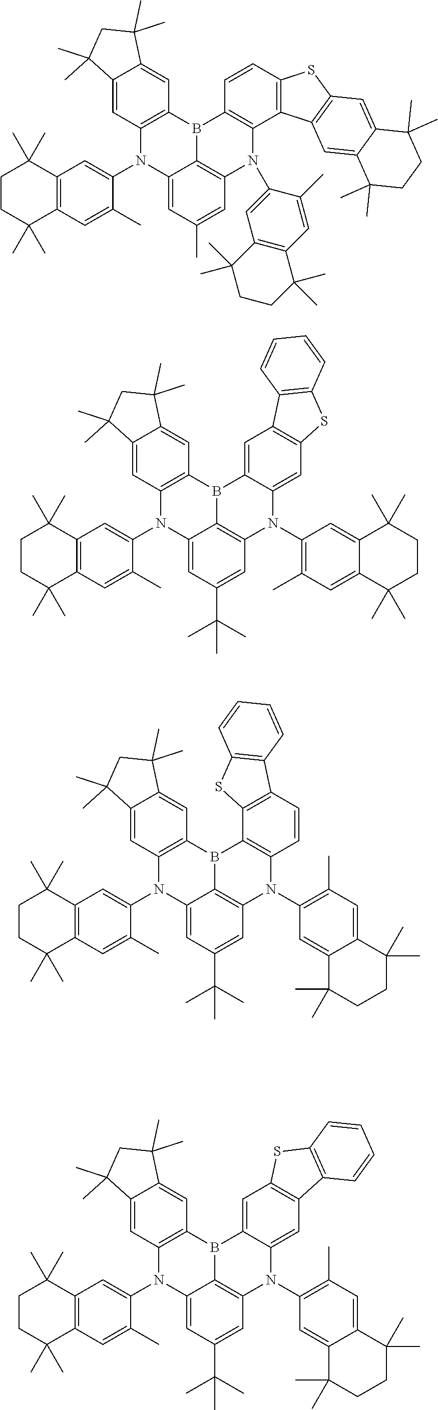

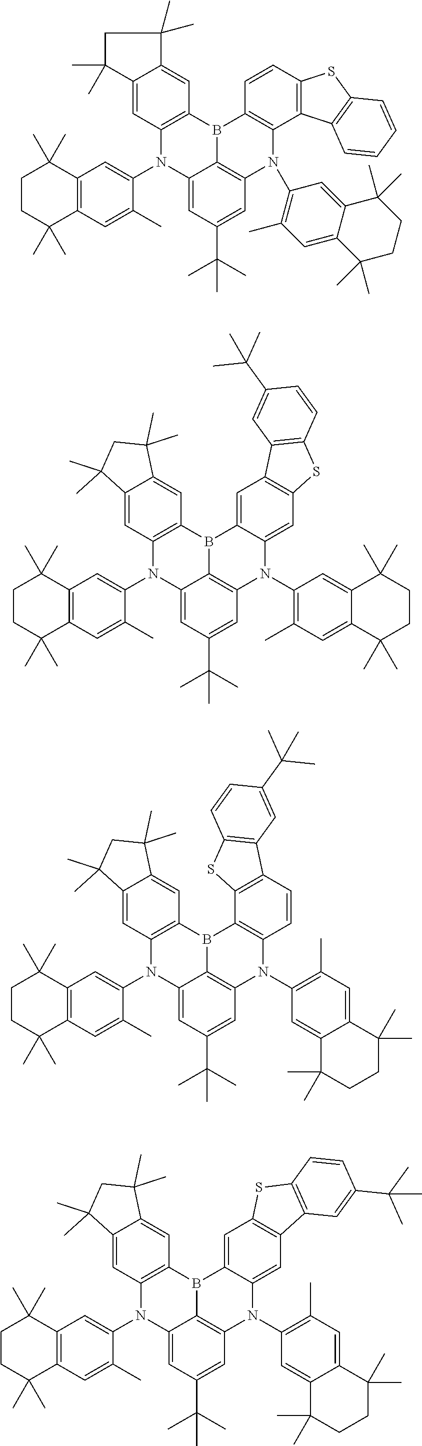

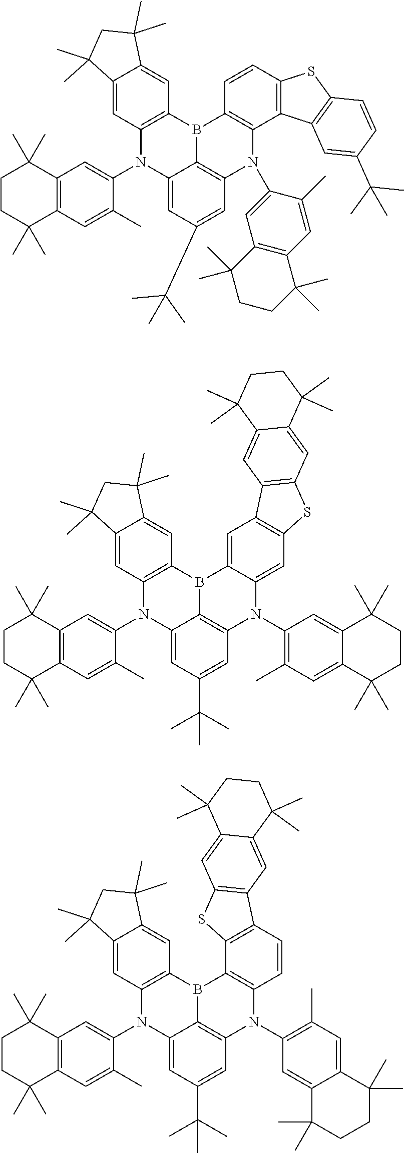

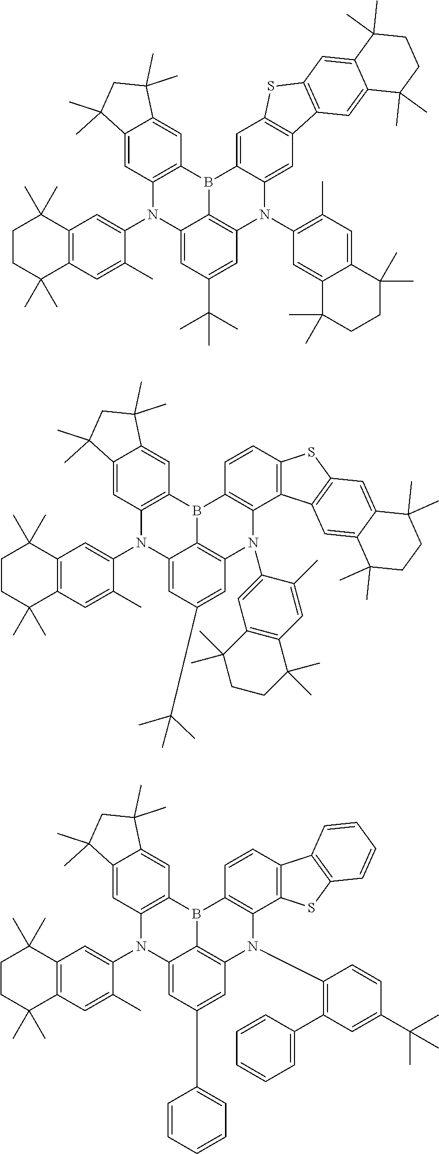

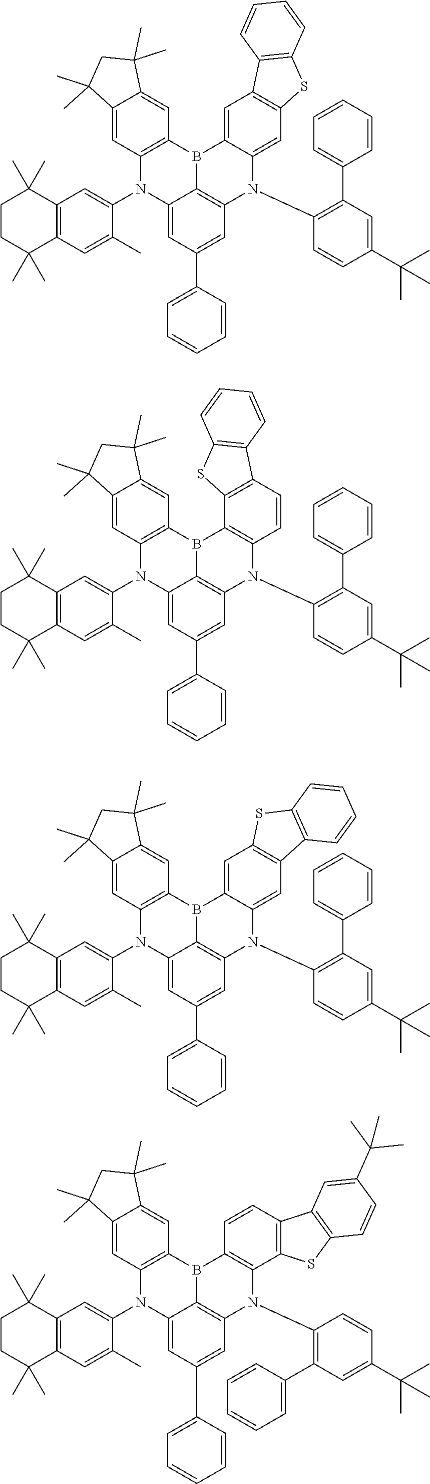

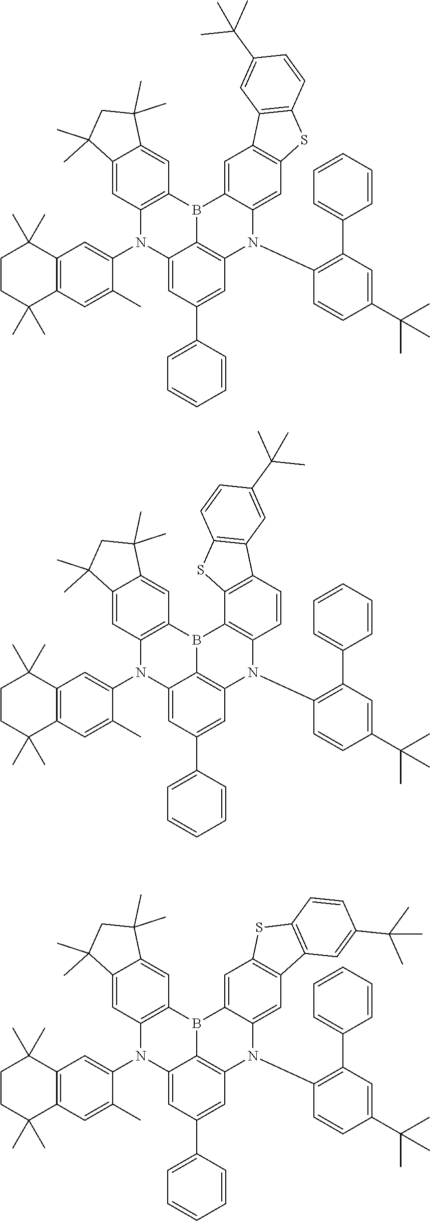 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(-c6ccccc6)cc1c53)C(C)(C)CC4(C)C)C(C)(C)CCC2(C)C]

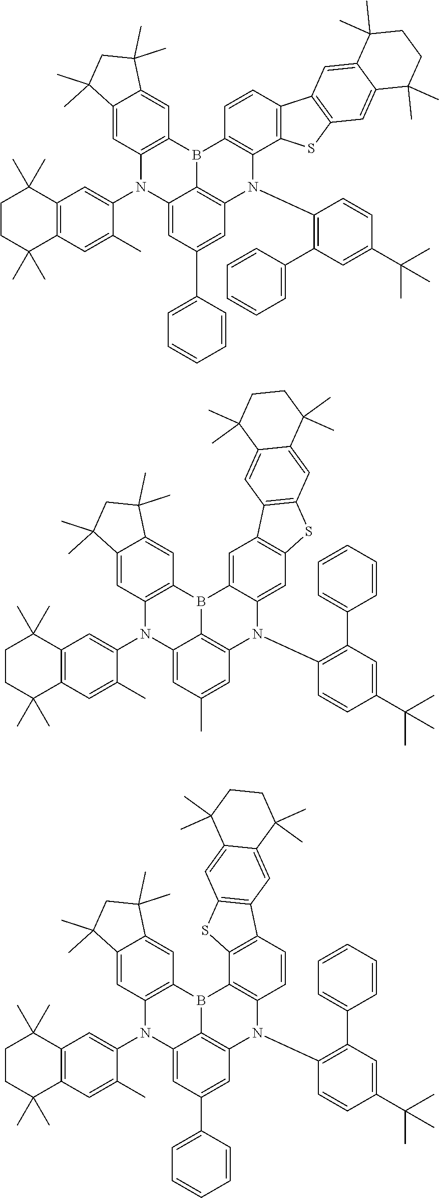 [SMILES: Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(-c6ccccc6)cc1c53)C(C)(C)CC4(C)C)C(C)(C)CCC2(C)C ; Cc1cc2c3c(c1)N(c1ccc(C(C)(C)C)cc1-c1ccccc1)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1cc2c(cc1N1c3cc4c(cc3B3c5c1cc(-c1ccccc1)cc5N(c1ccc(C(C)(C)C)cc1-c1ccccc1)c1ccc5c(sc6cc7c(cc65)C(C)(C)CCC7(C)C)c13)C(C)(C)CC4(C)C)C(C)(C)CCC2(C)C]

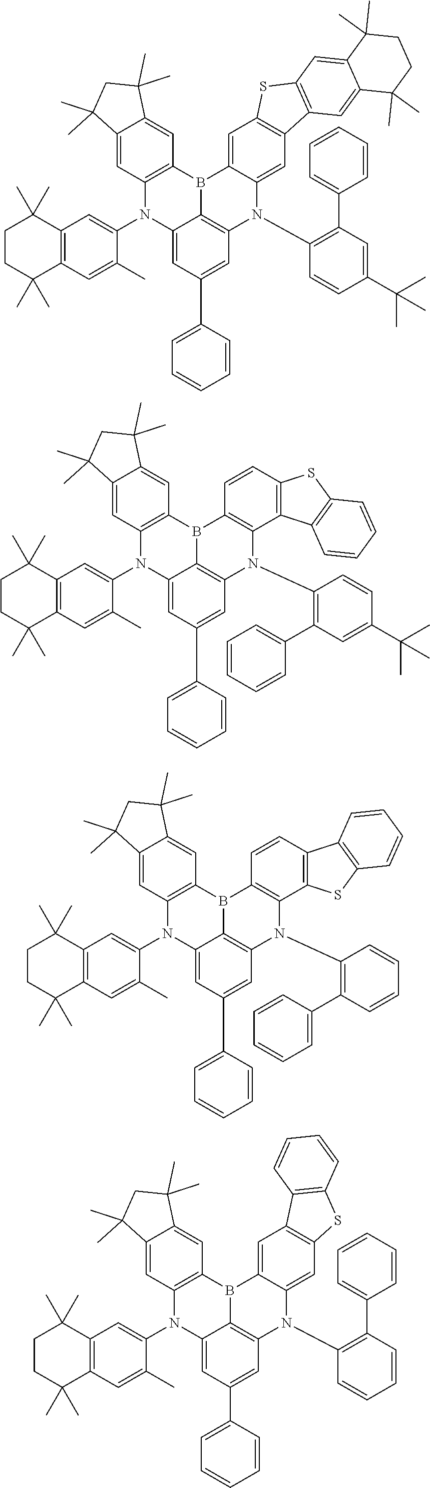

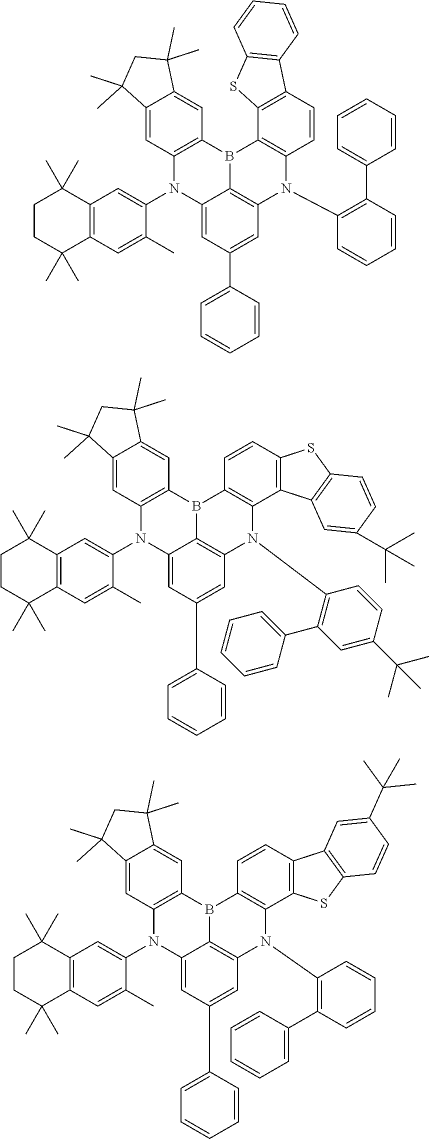 [SMILES: Cc1cc2c(cc1N1c3cc4c(cc3B3c5c1cc(-c1ccccc1)cc5N(c1ccccc1-c1ccccc1)c1ccc5c(sc6ccccc65)c13)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(-c6ccccc6)cc1c53)C(C)(C)CC4(C)C)C(C)(C)CCC2(C)C]

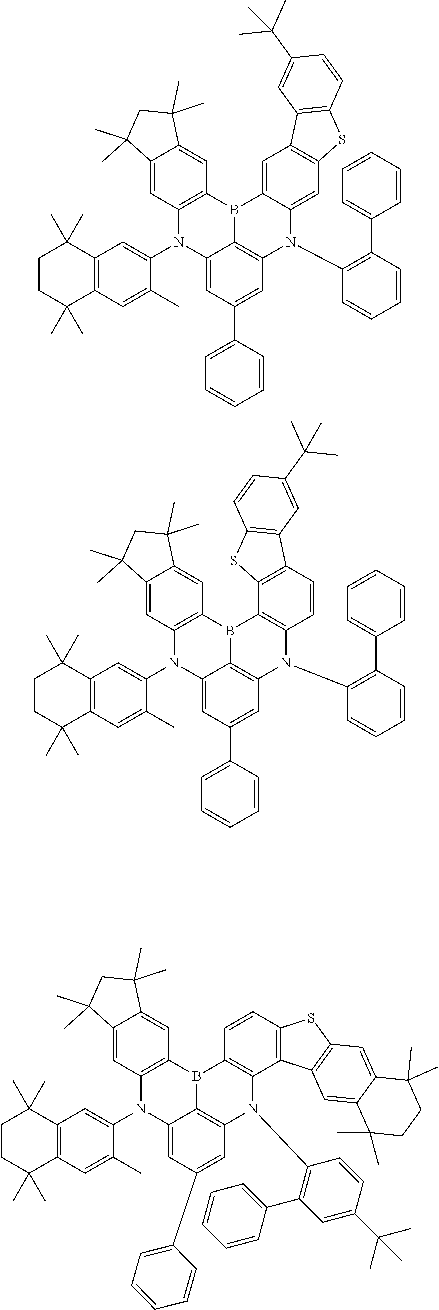

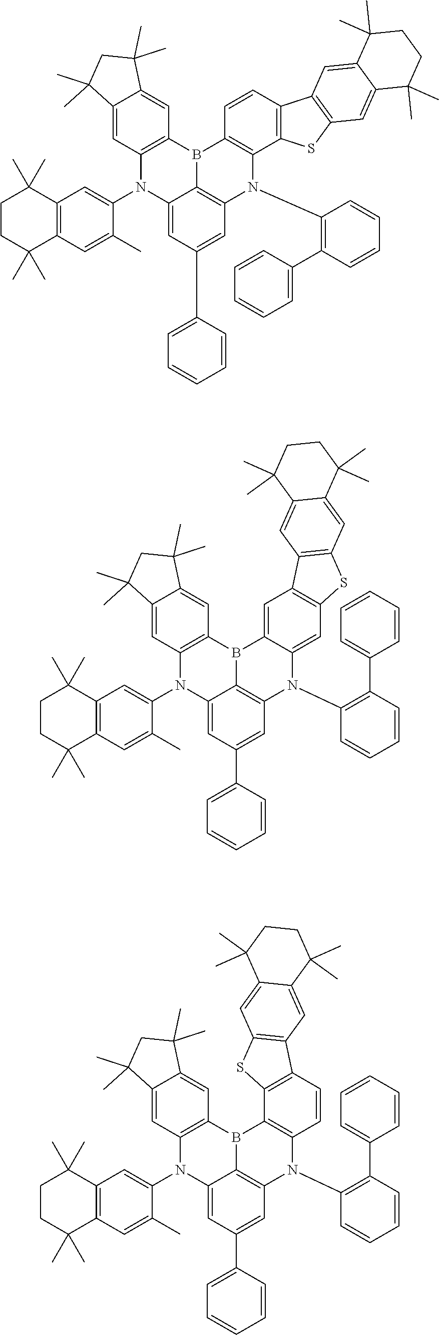 [SMILES: Cc1cc2c(cc1N1c3cc4c(cc3B3c5ccc6c(sc7cc8c(cc76)C(C)(C)CCC8(C)C)c5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)sc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(sc6cc7c(cc65)C(C)(C)CCC7(C)C)c13)C(C)(C)CC4(C)C)C(C)(C)CCC2(C)C]

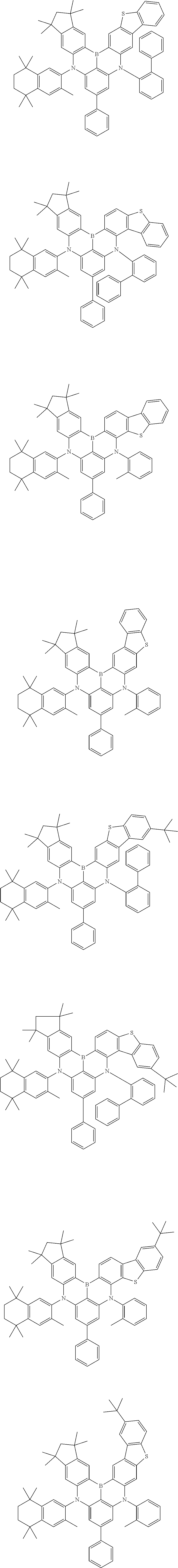

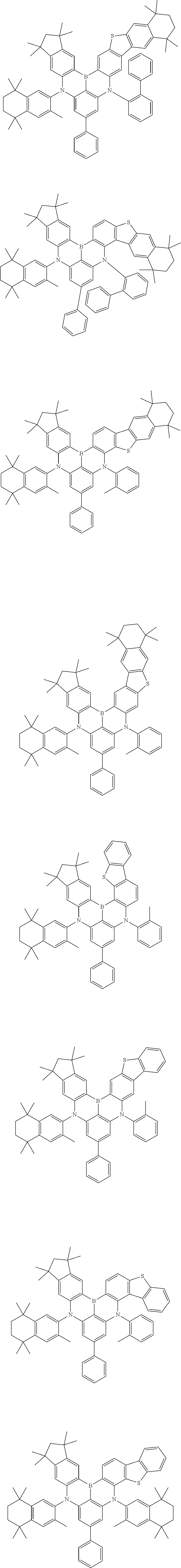

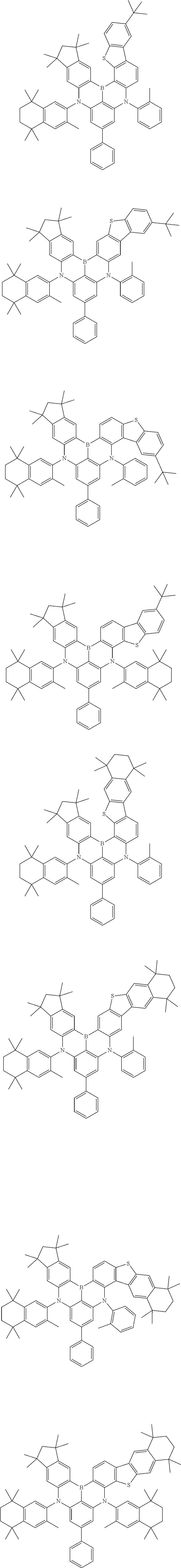

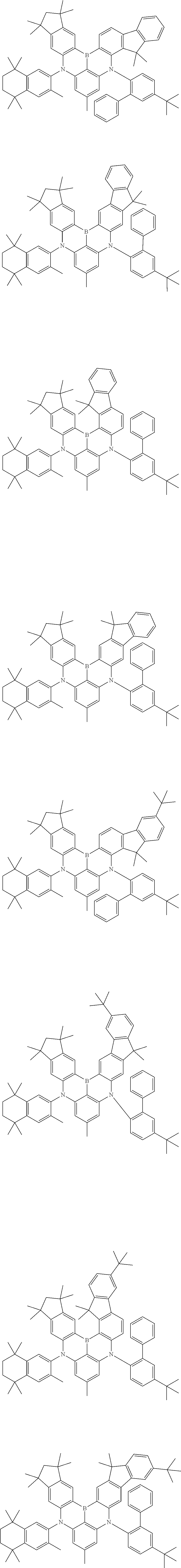

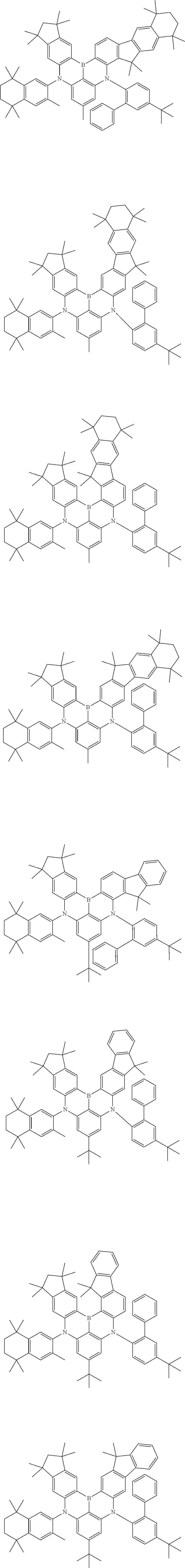

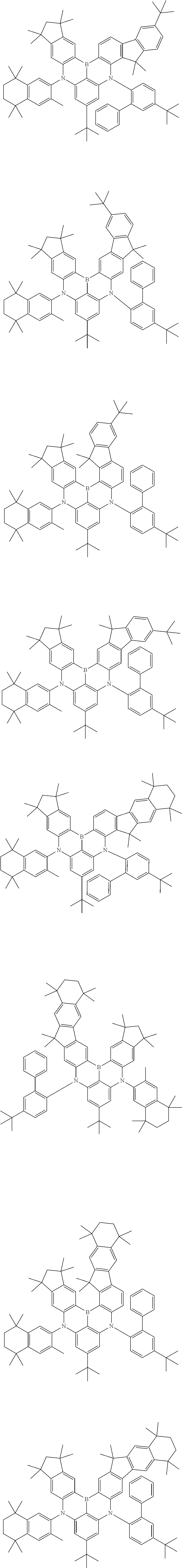

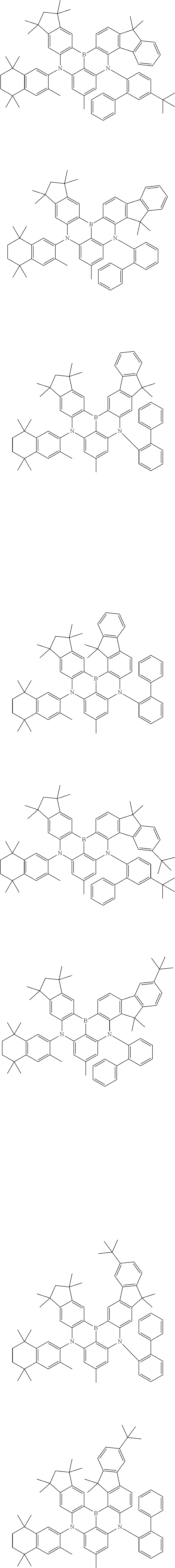

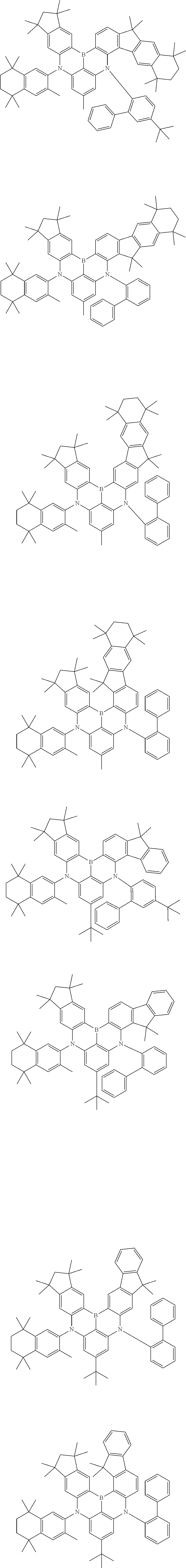

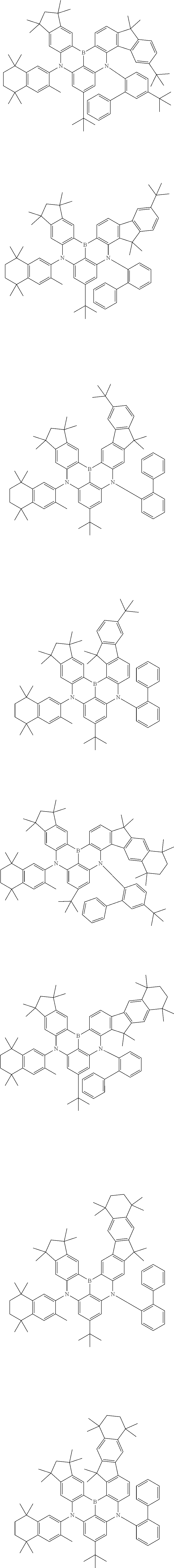

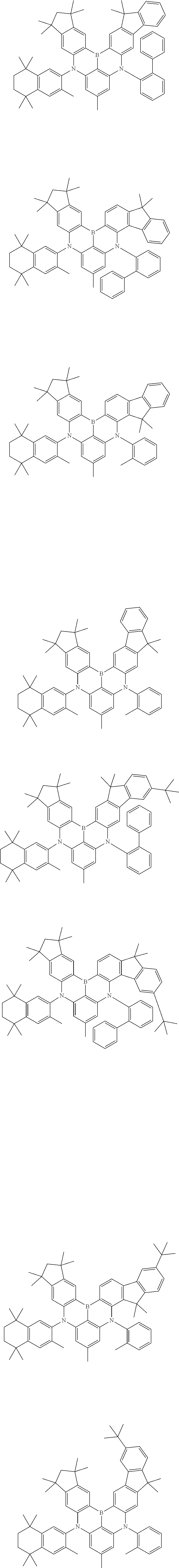

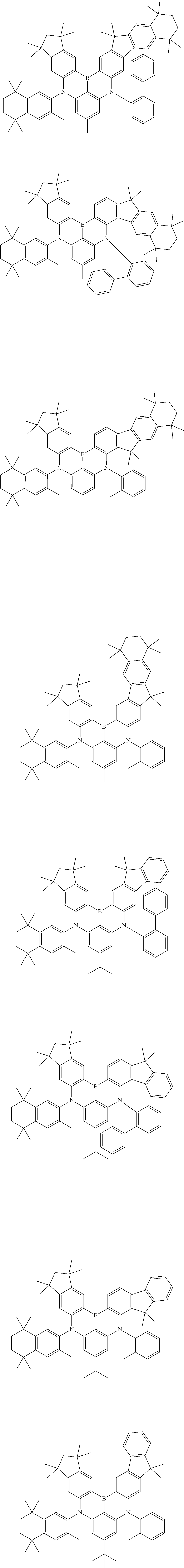

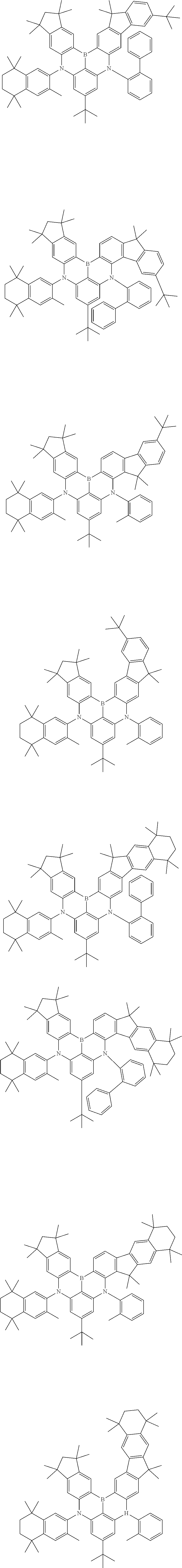

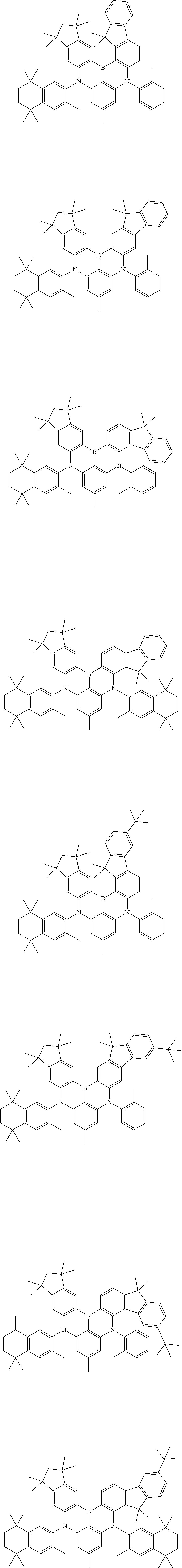

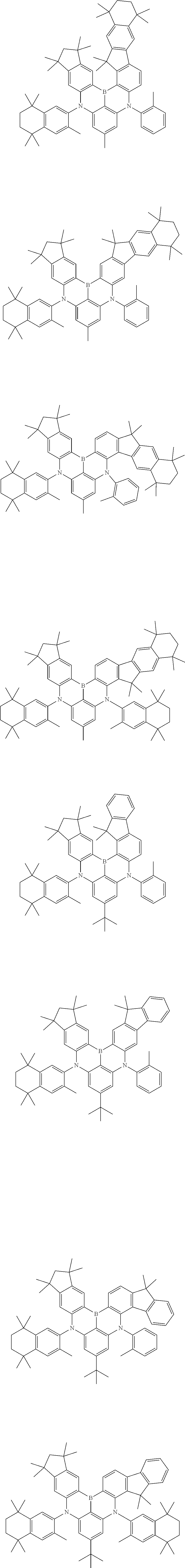

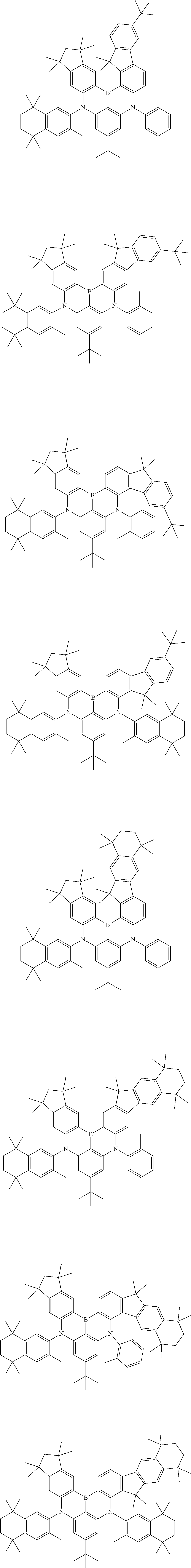

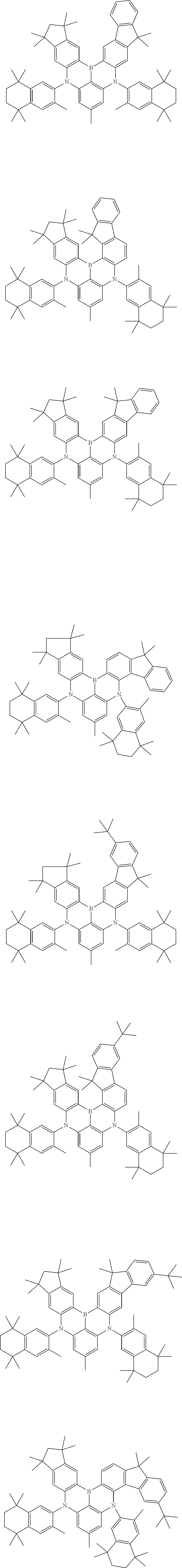

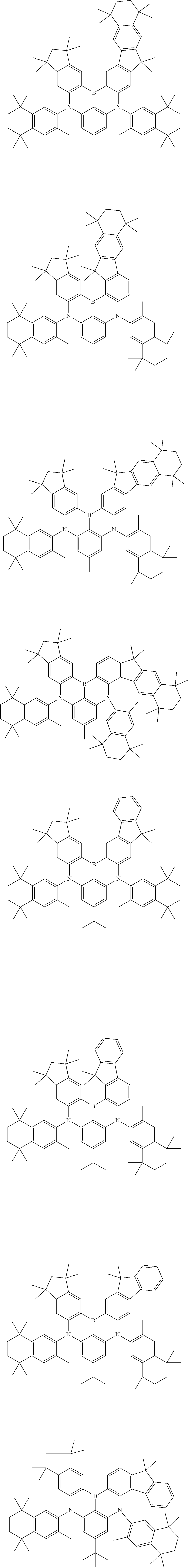

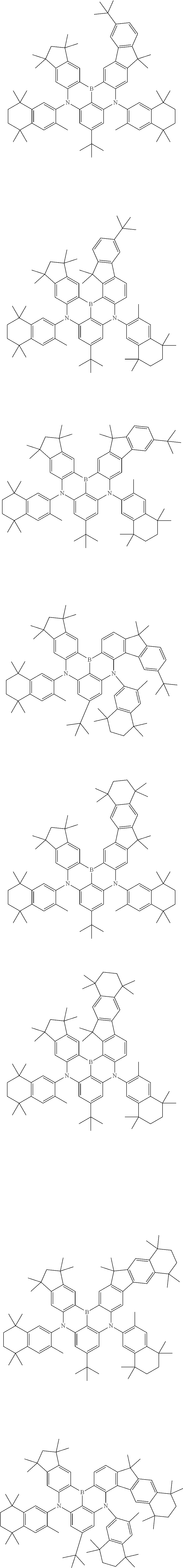

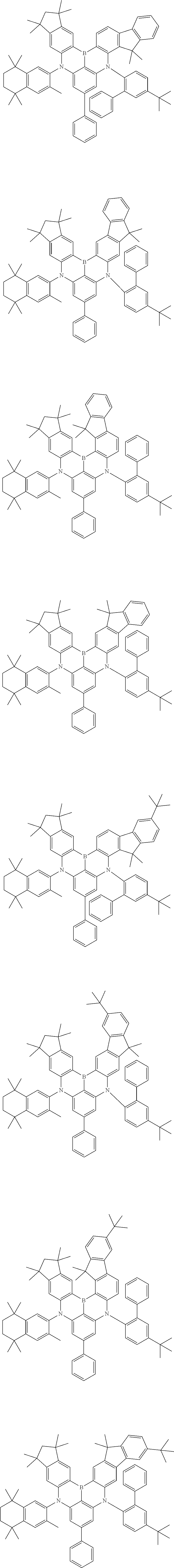

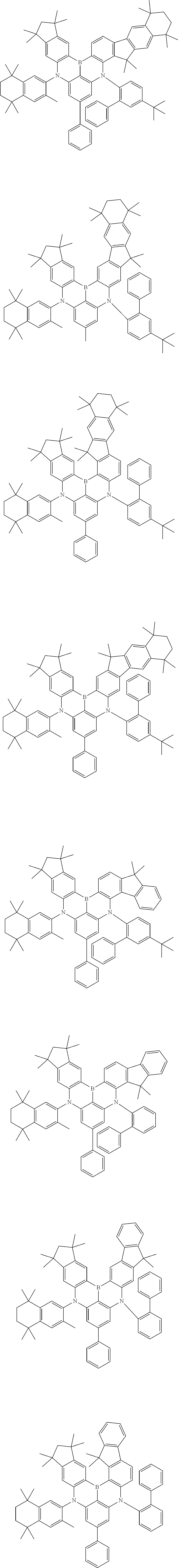

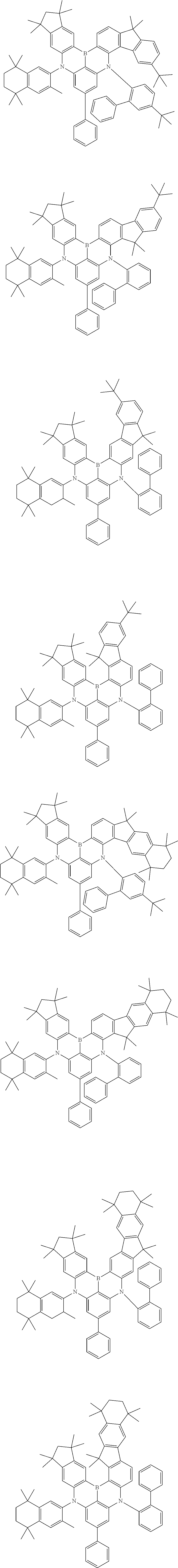

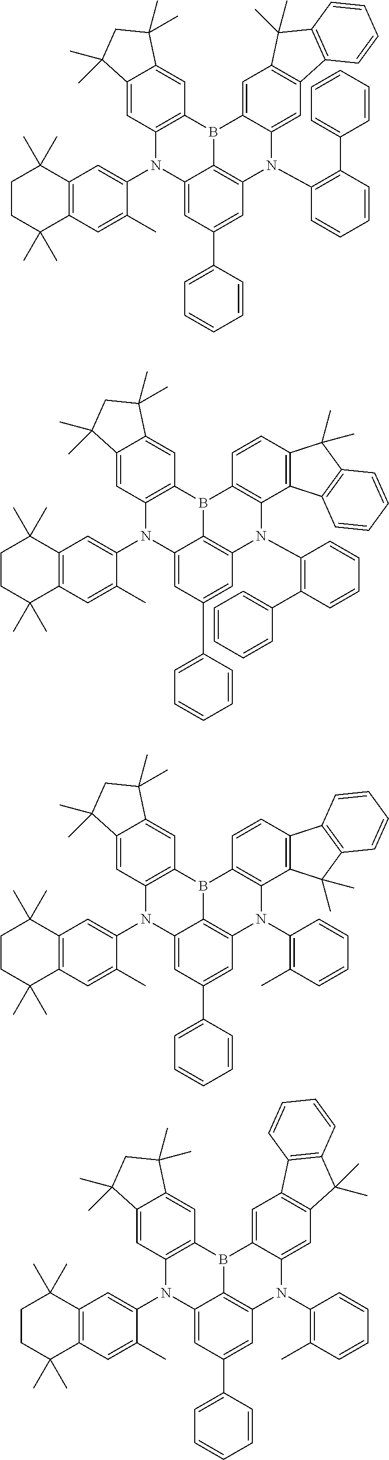 [SMILES: Cc1cc2c(cc1N1c3cc4c(cc3B3c5cc6c(cc5N(c5ccccc5-c5ccccc5)c5cc(-c7ccccc7)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5C)c5cc(-c7ccccc7)cc1c53)C(C)(C)c1ccccc1-6)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)-c1ccccc1C3(C)C]

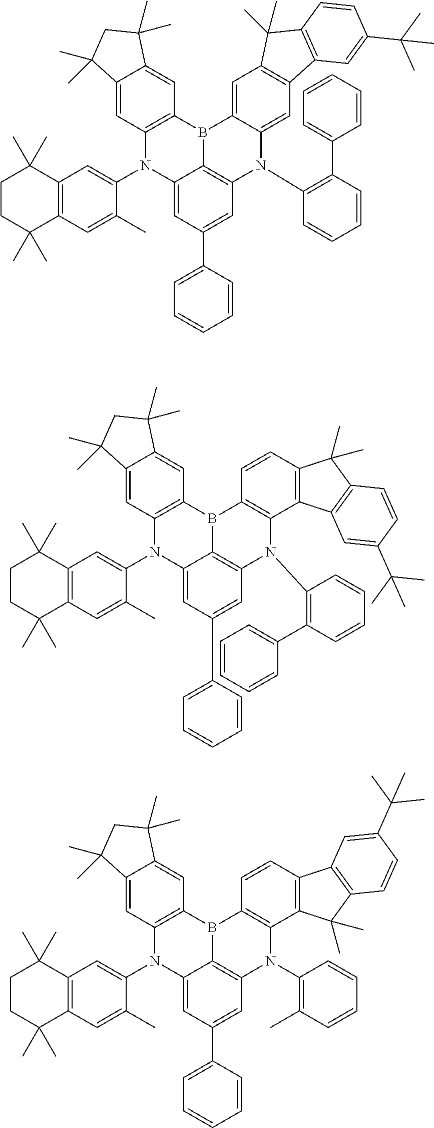 [SMILES: Cc1cc2c(cc1N1c3cc4c(cc3B3c5cc6c(cc5N(c5ccccc5-c5ccccc5)c5cc(-c7ccccc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5C)c5cc(-c7ccccc7)cc1c53)C(C)(C)c1ccc(C(C)(C)C)cc1-6)C(C)(C)CC4(C)C)C(C)(C)CCC2(C)C]

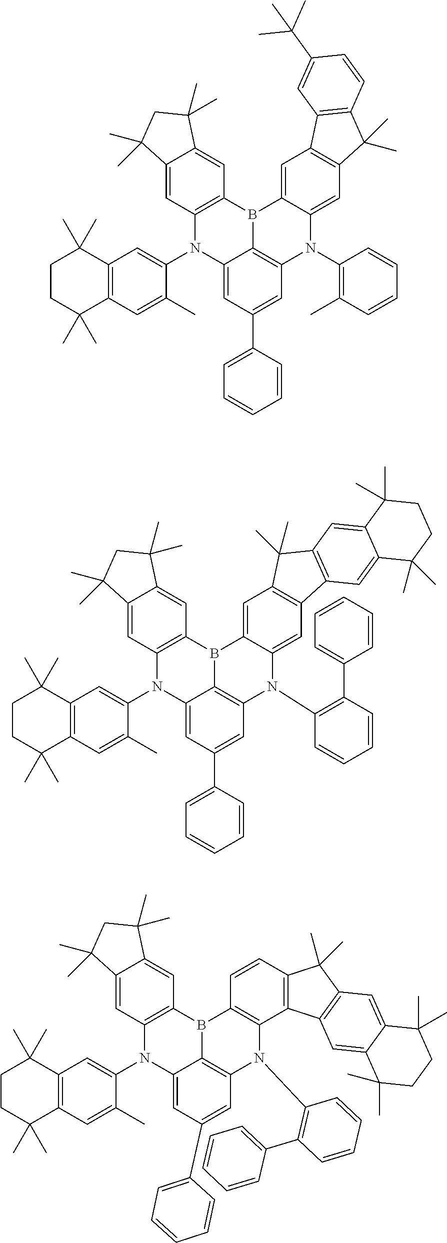 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)-c1cc(C(C)(C)C)ccc1C3(C)C ; Cc1cc2c(cc1N1c3cc4c(cc3B3c5cc6c(cc5N(c5ccccc5-c5ccccc5)c5cc(-c7ccccc7)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1cc3c(cc1C6(C)C)C(C)(C)CCC3(C)C)C(C)(C)CC4(C)C)C(C)(C)CCC2(C)C]

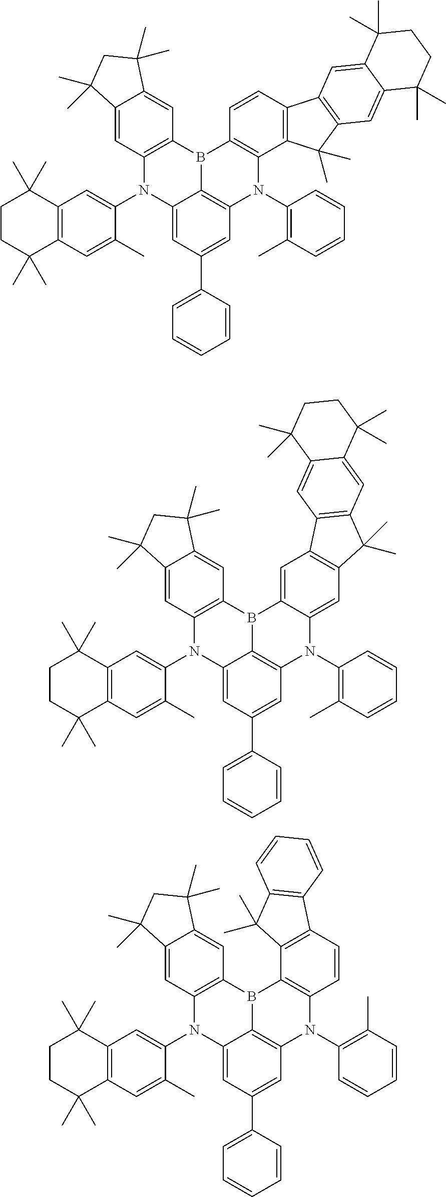

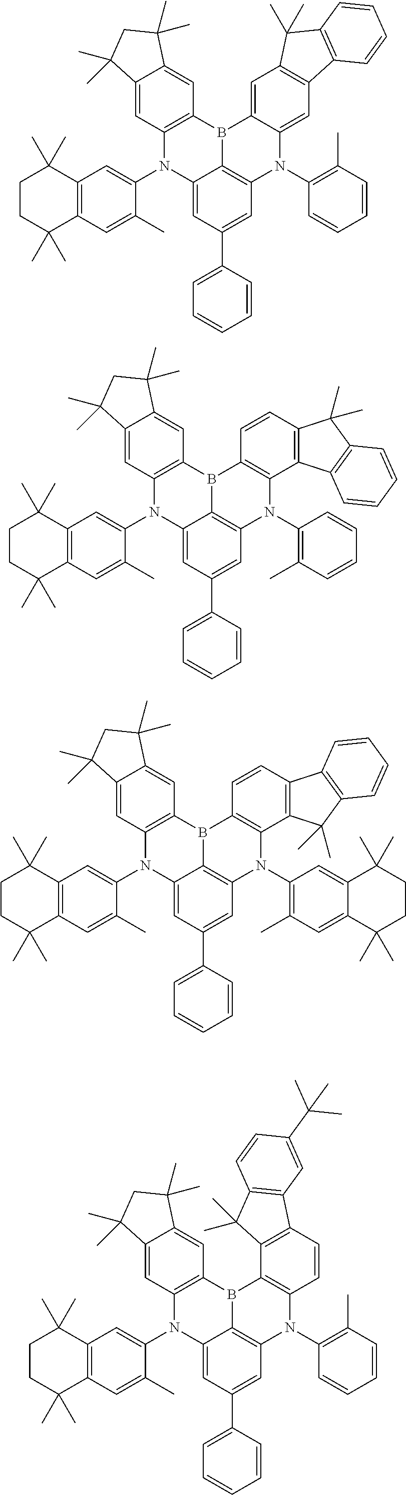

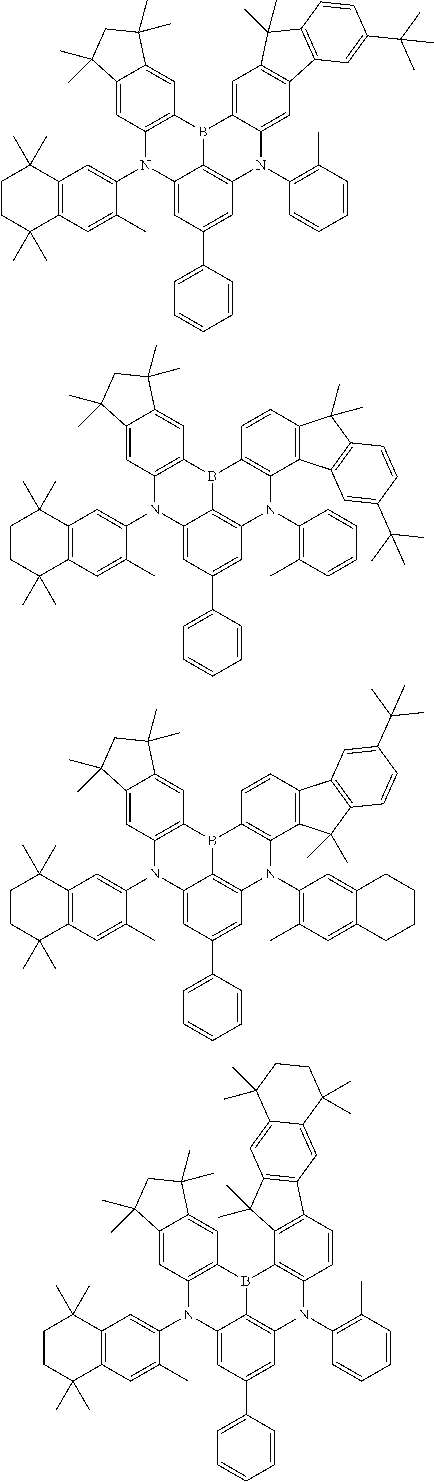

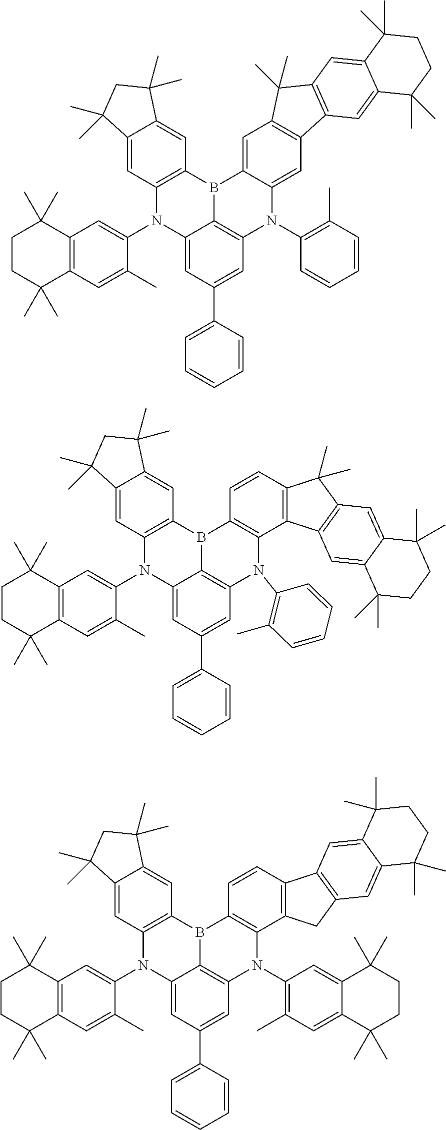 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)C(C)(C)c1cc2c(cc1-3)C(C)(C)CCC2(C)C ; Cc1cc2c(cc1N1c3cc4c(cc3B3c5ccc6c(c5N(c5ccccc5C)c5cc(-c7ccccc7)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7ccccc7)cc1c53)Cc1cc3c(cc1-6)C(C)(C)CCC3(C)C)C(C)(C)CC4(C)C)C(C)(C)CCC2(C)C]

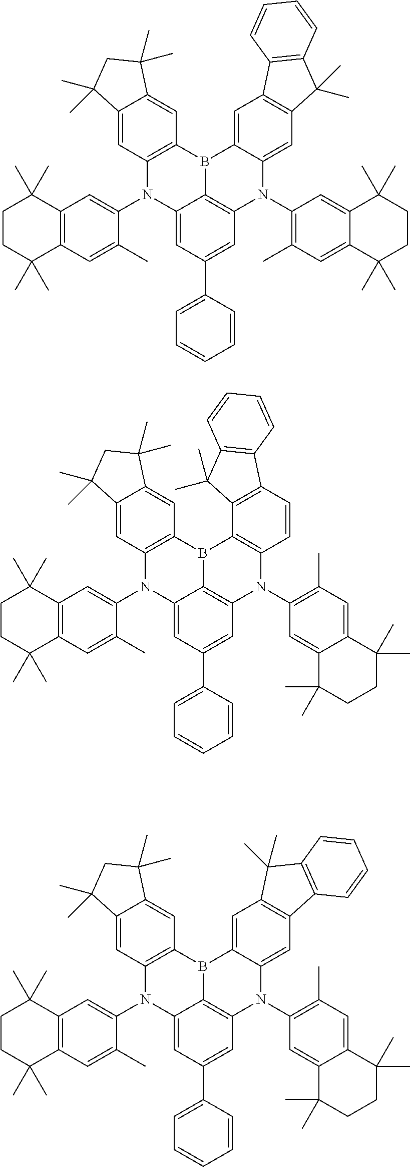

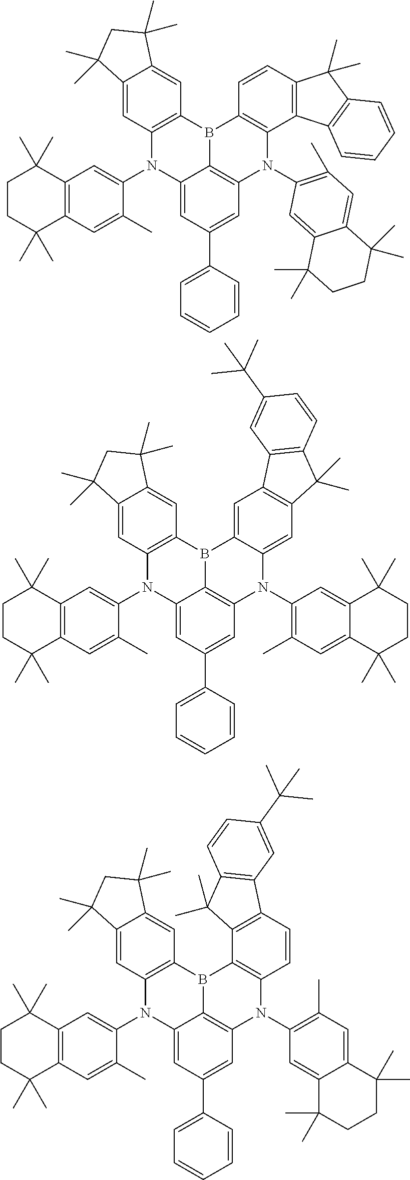

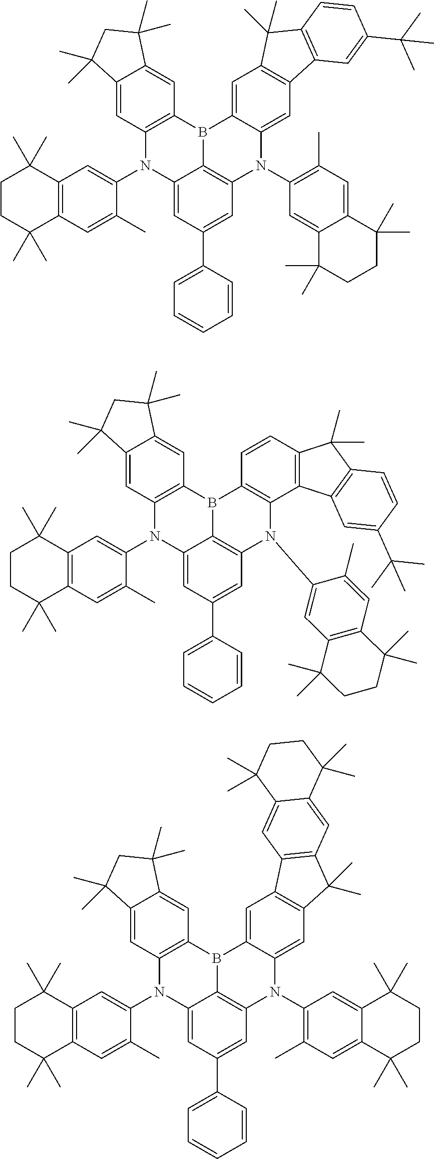

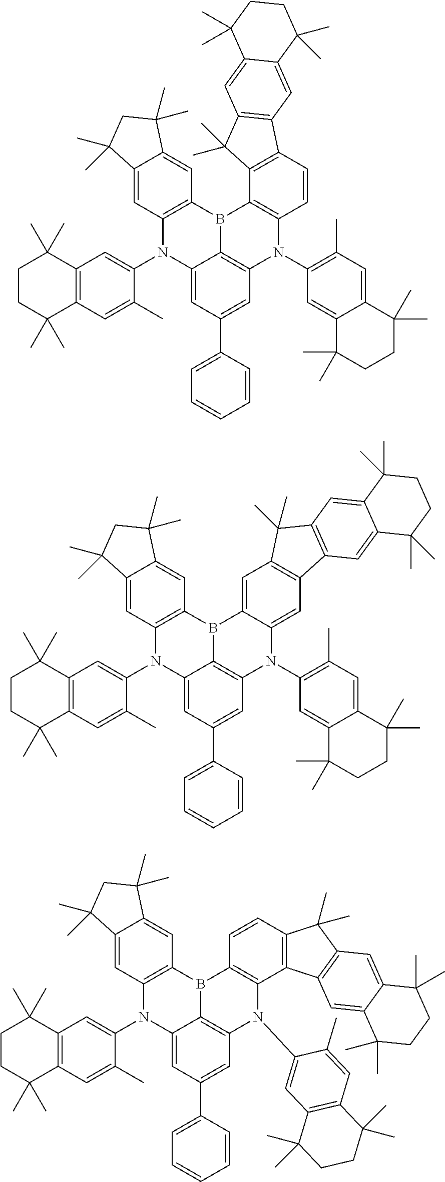 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(c13)C(C)(C)c1cc3c(cc1-5)C(C)(C)CCC3(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)CC6(C)C)C(C)(C)c1cc3c(cc1-4)C(C)(C)CCC3(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7ccccc7)cc1c53)-c1cc3c(cc1C6(C)C)C(C)(C)CCC3(C)C)C(C)(C)CC4(C)C)C(C)(C)CCC2(C)C]

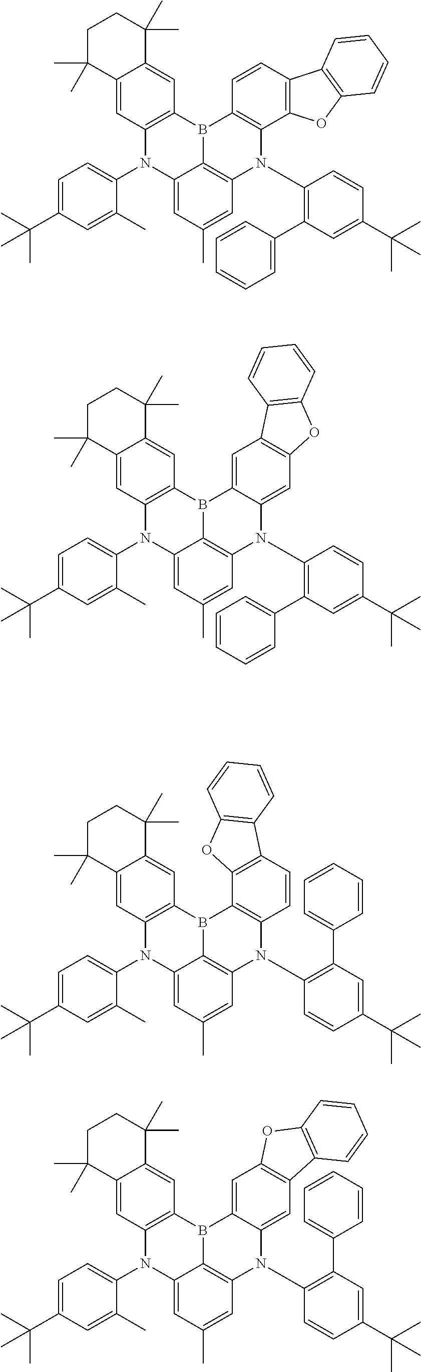

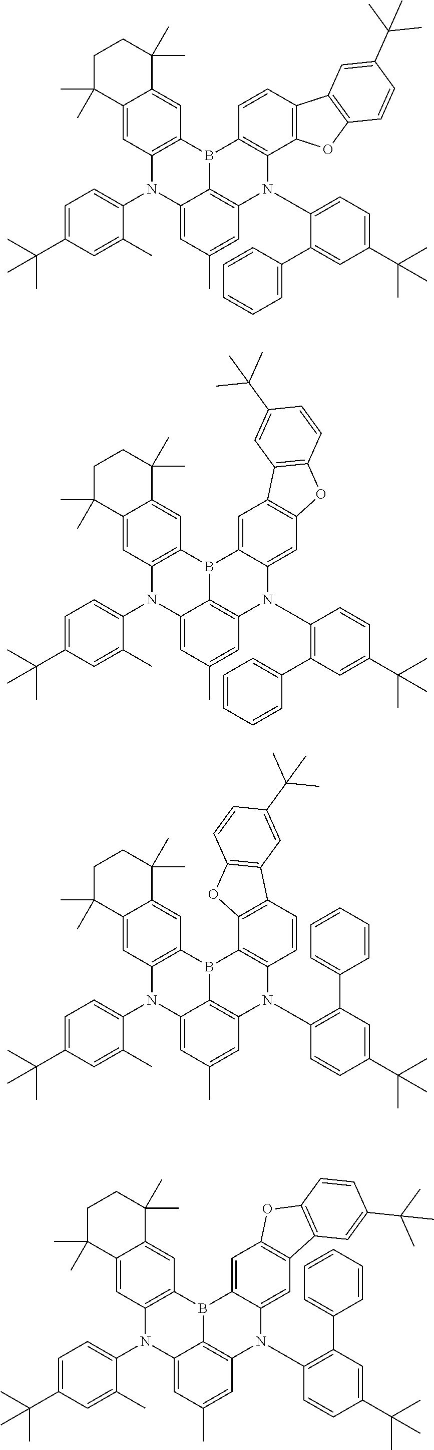

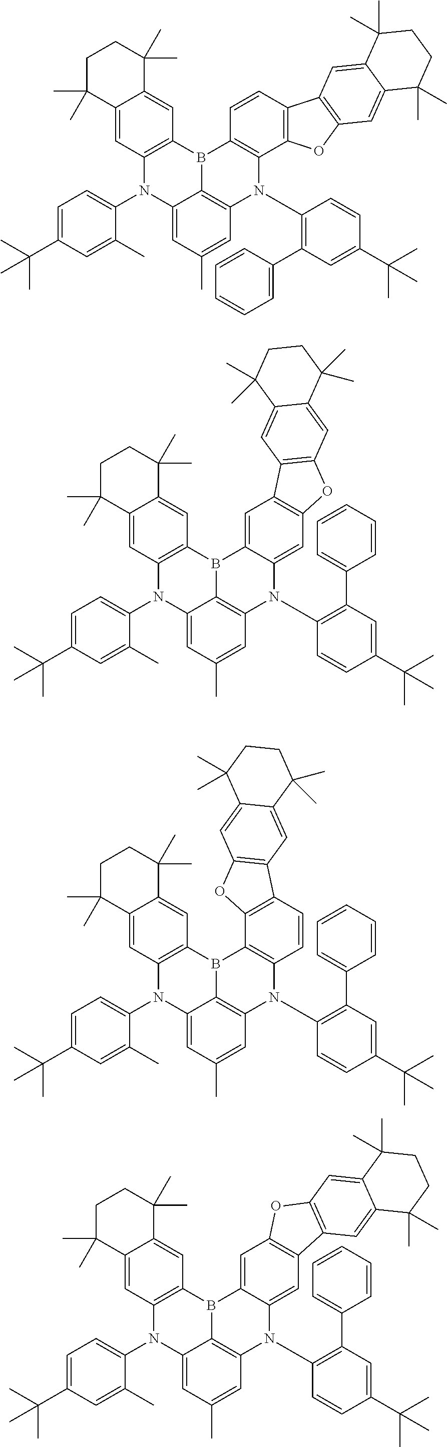

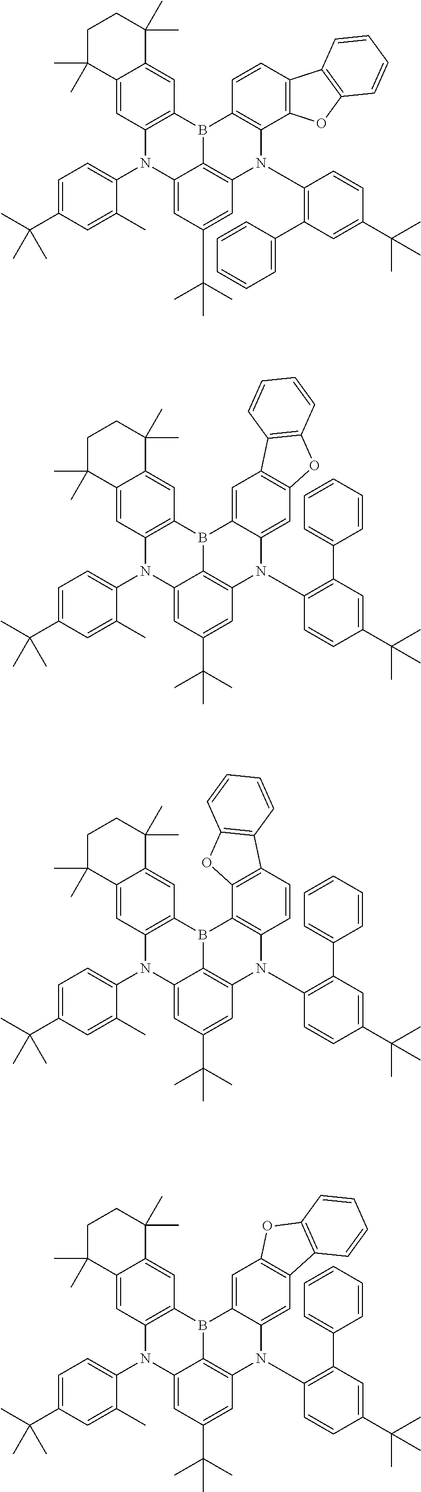

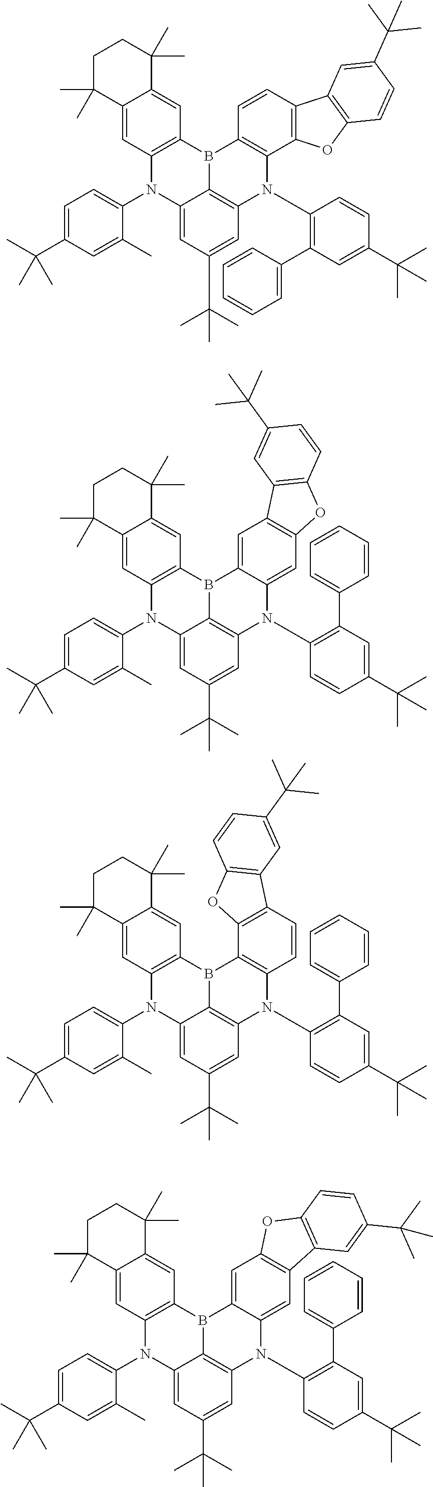

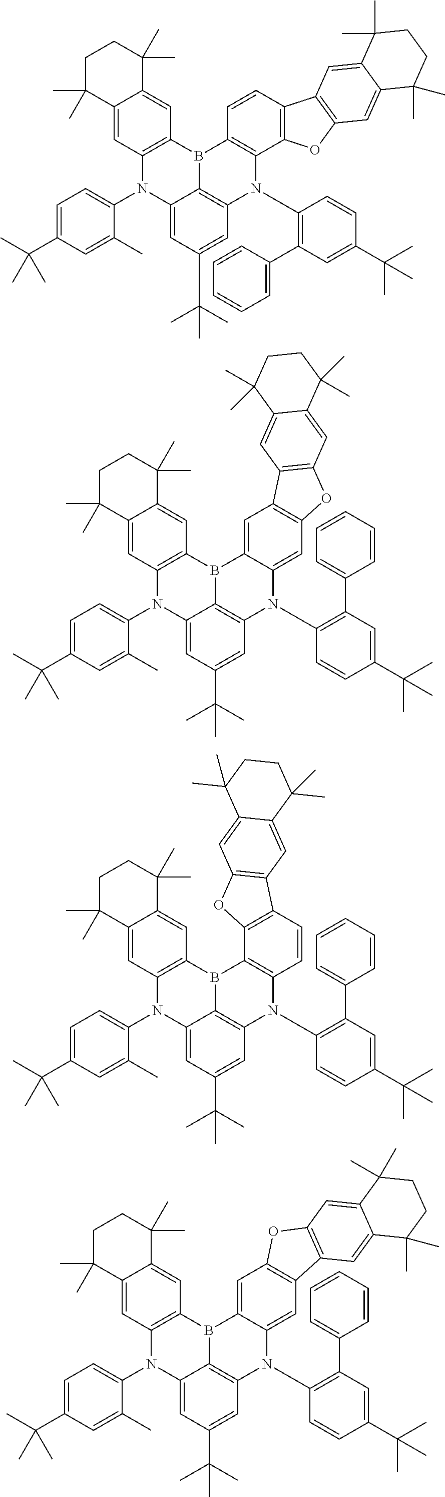

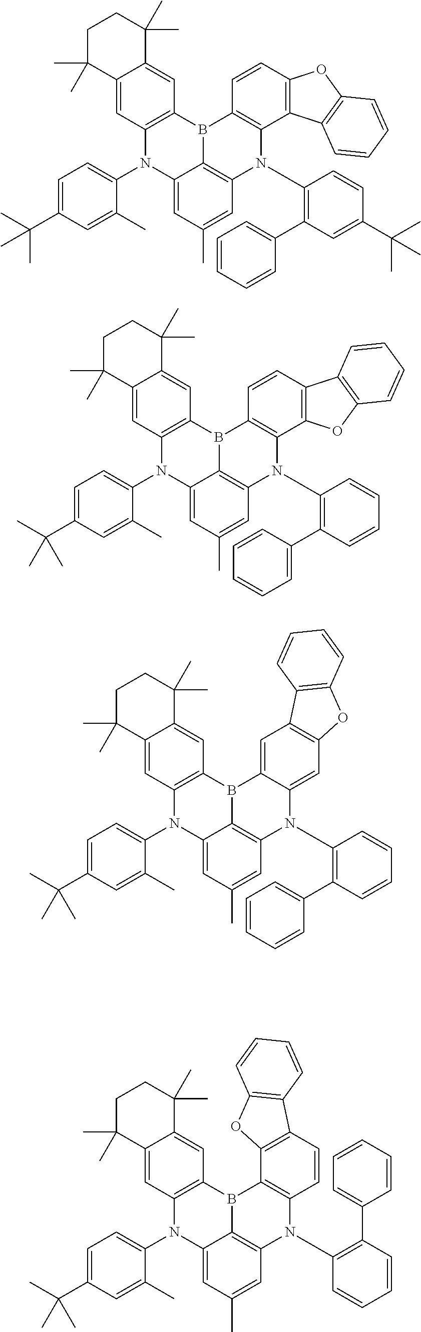

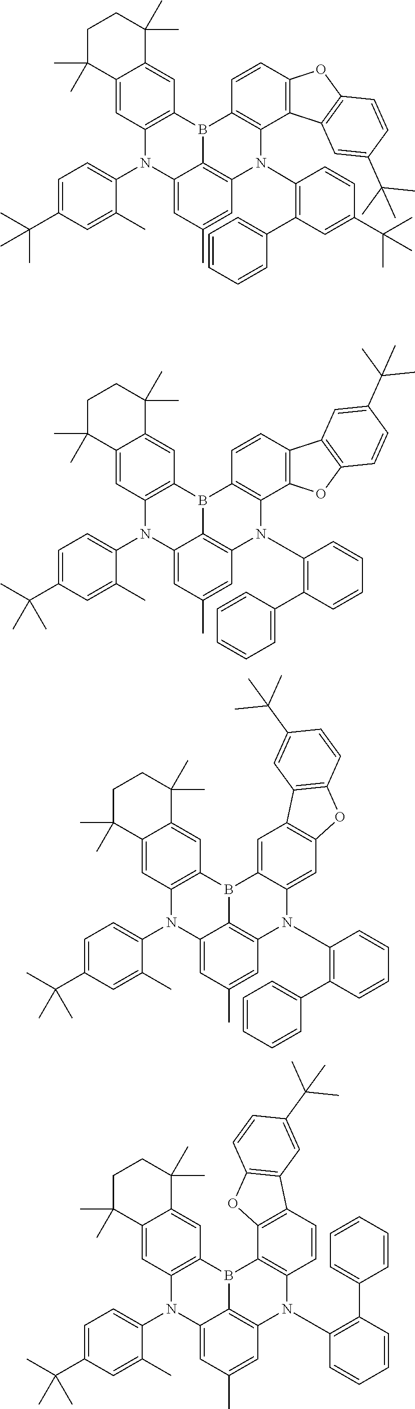

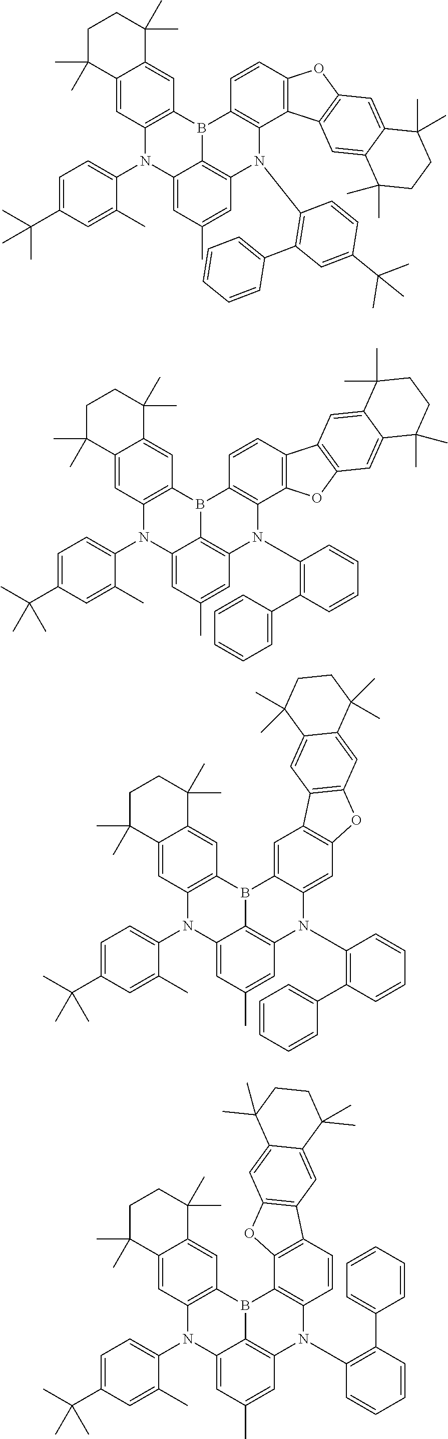

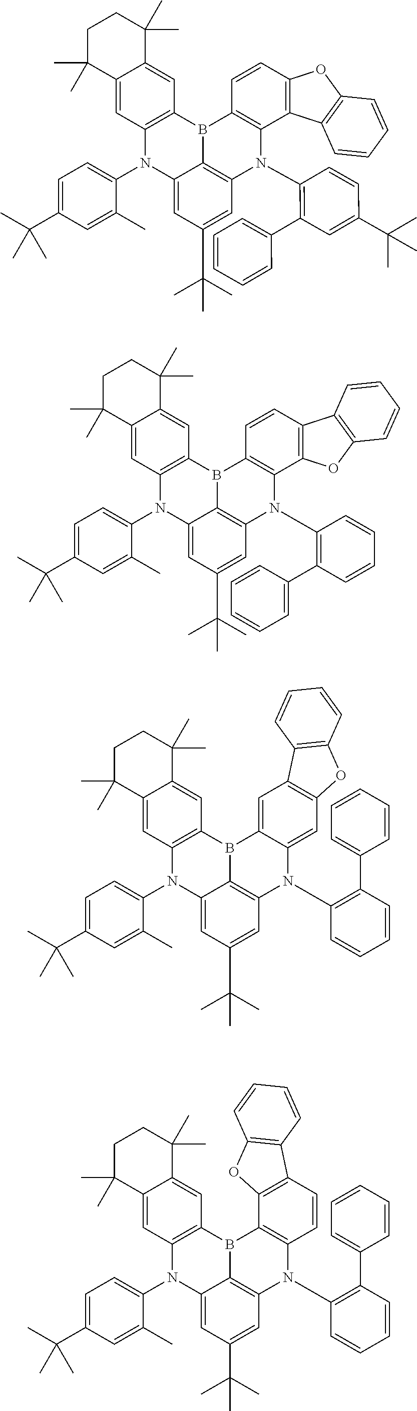

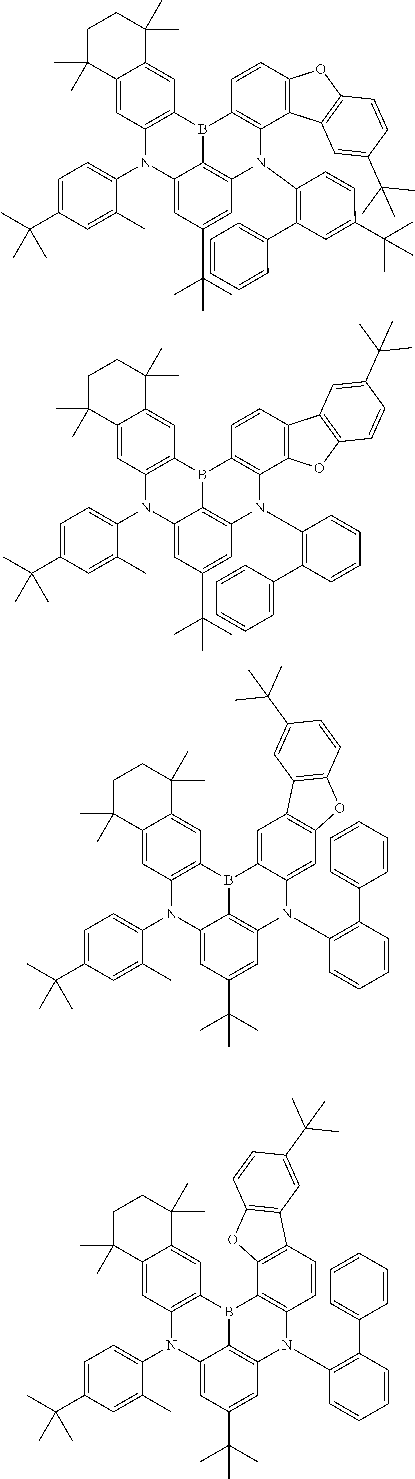

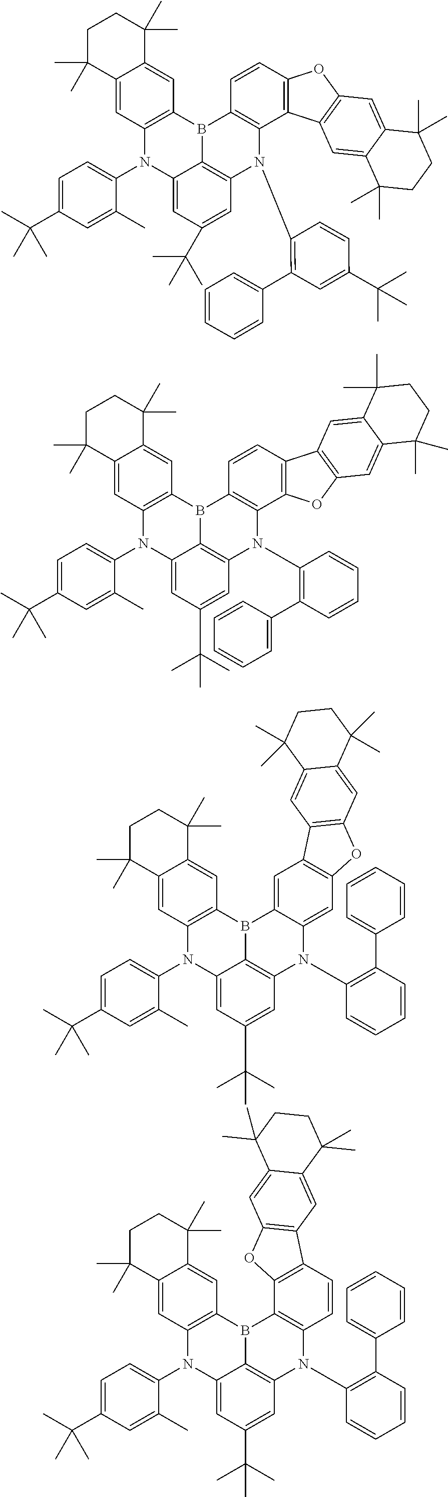

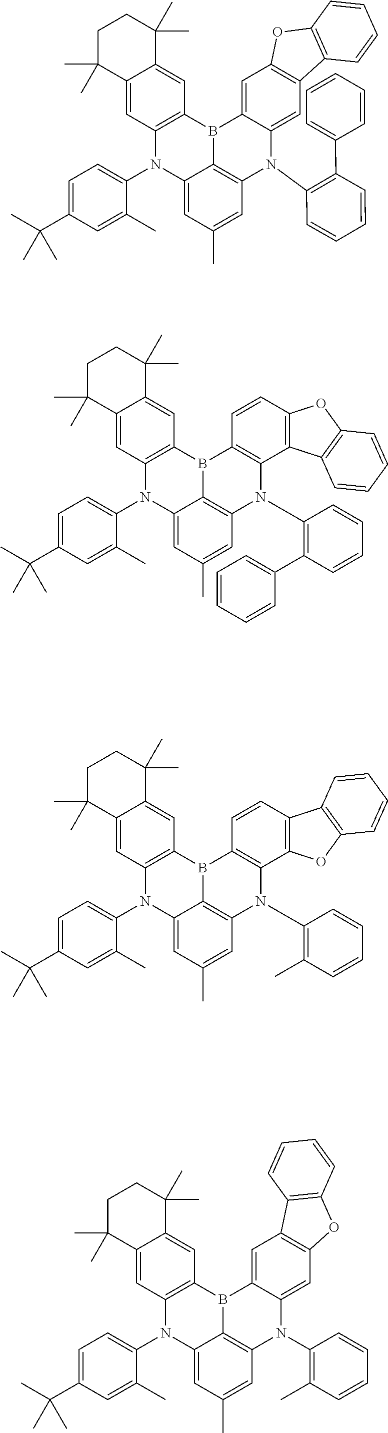 [SMILES: Cc1cc2c3c(c1)N(c1ccccc1-c1ccccc1)c1cc4c(cc1B3c1cc3c(cc1N2c1ccc(C(C)(C)C)cc1C)C(C)(C)CCC3(C)C)oc1ccccc14 ; Cc1cc2c3c(c1)N(c1ccccc1-c1ccccc1)c1c(ccc4oc5ccccc5c14)B3c1cc3c(cc1N2c1ccc(C(C)(C)C)cc1C)C(C)(C)CCC3(C)C ; Cc1cc2c3c(c1)N(c1ccccc1C)c1c(ccc4c1oc1ccccc14)B3c1cc3c(cc1N2c1ccc(C(C)(C)C)cc1C)C(C)(C)CCC3(C)C ; Cc1cc2c3c(c1)N(c1ccccc1C)c1cc4oc5ccccc5c4cc1B3c1cc3c(cc1N2c1ccc(C(C)(C)C)cc1C)C(C)(C)CCC3(C)C]

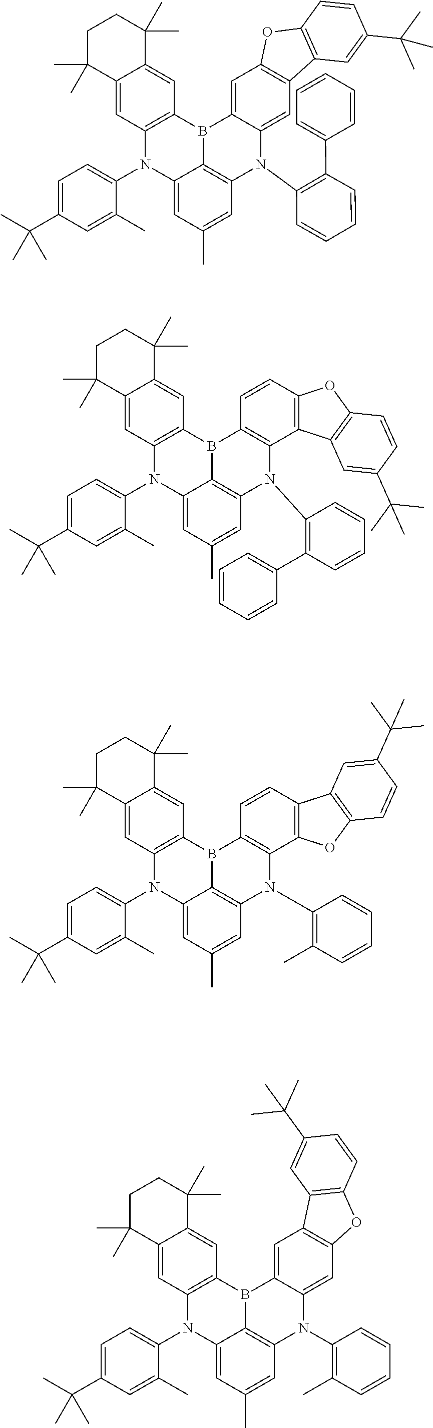

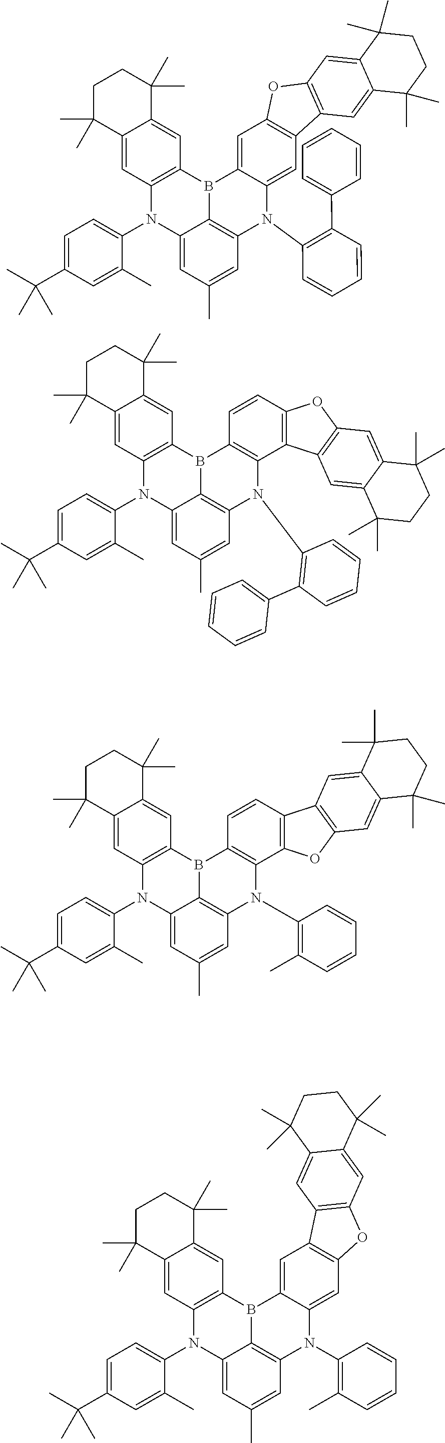

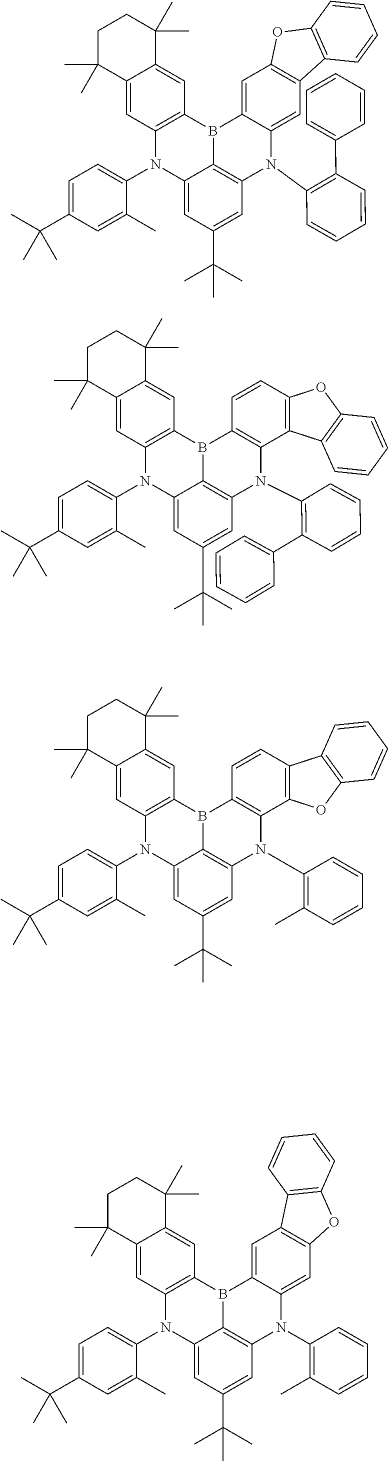

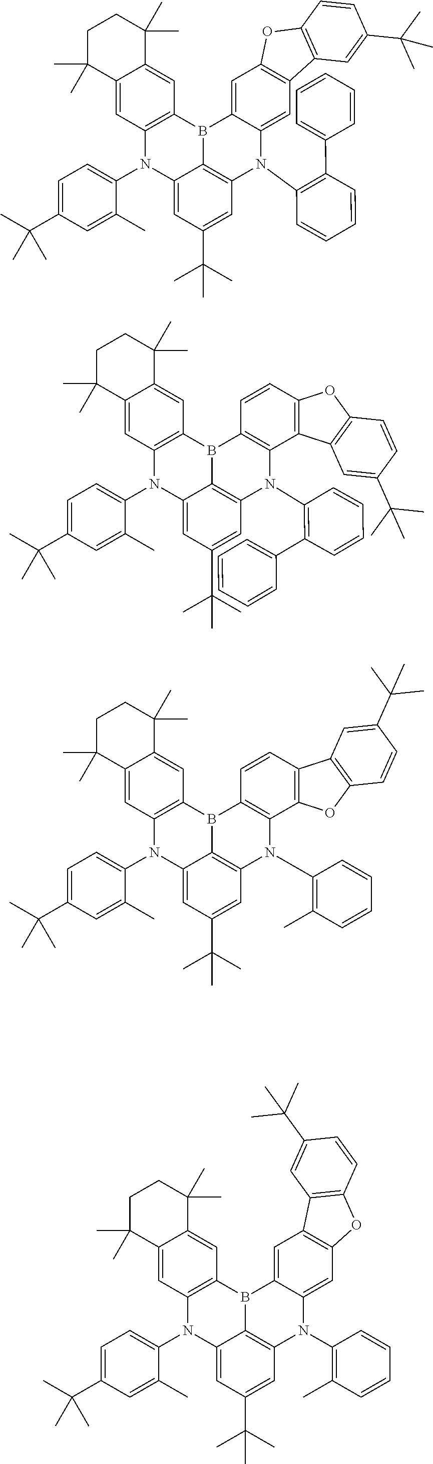

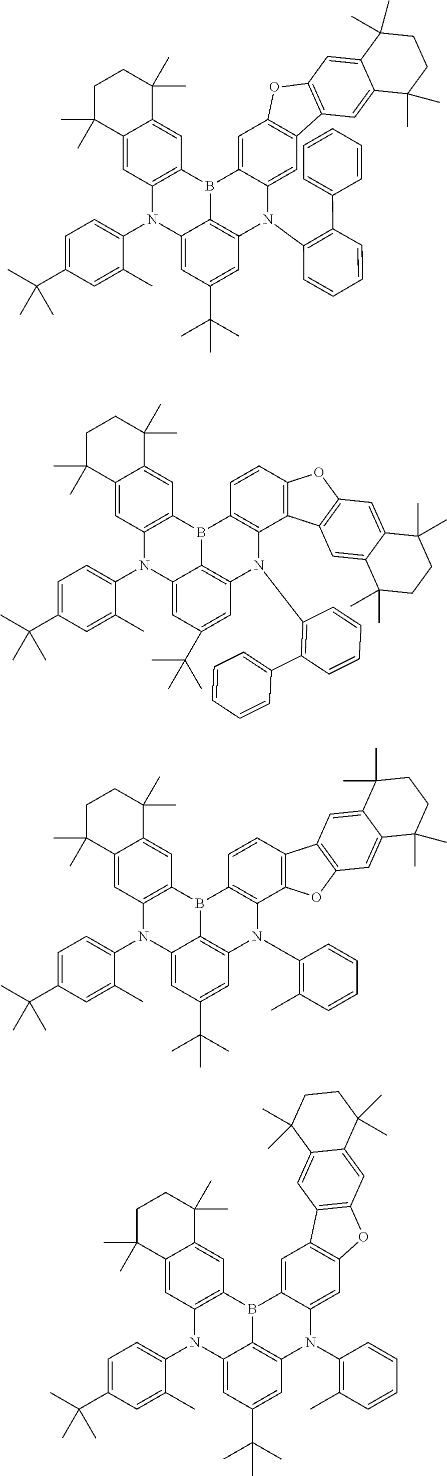

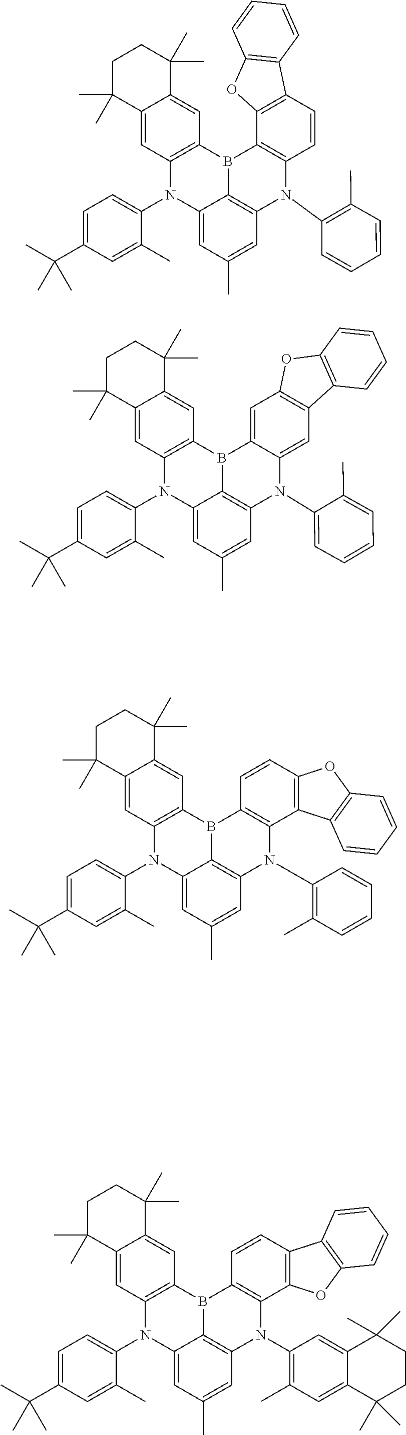 [SMILES: Cc1cc2c3c(c1)N(c1ccccc1C)c1ccc4c(oc5ccccc54)c1B3c1cc3c(cc1N2c1ccc(C(C)(C)C)cc1C)C(C)(C)CCC3(C)C ; Cc1cc2c3c(c1)N(c1ccccc1C)c1cc4c(cc1B3c1cc3c(cc1N2c1ccc(C(C)(C)C)cc1C)C(C)(C)CCC3(C)C)oc1ccccc14 ; Cc1cc2c3c(c1)N(c1ccccc1C)c1c(ccc4oc5ccccc5c14)B3c1cc3c(cc1N2c1ccc(C(C)(C)C)cc1C)C(C)(C)CCC3(C)C ; Cc1cc2c3c(c1)N(c1cc4c(cc1C)C(C)(C)CCC4(C)C)c1c(ccc4c1oc1ccccc14)B3c1cc3c(cc1N2c1ccc(C(C)(C)C)cc1C)C(C)(C)CCC3(C)C]

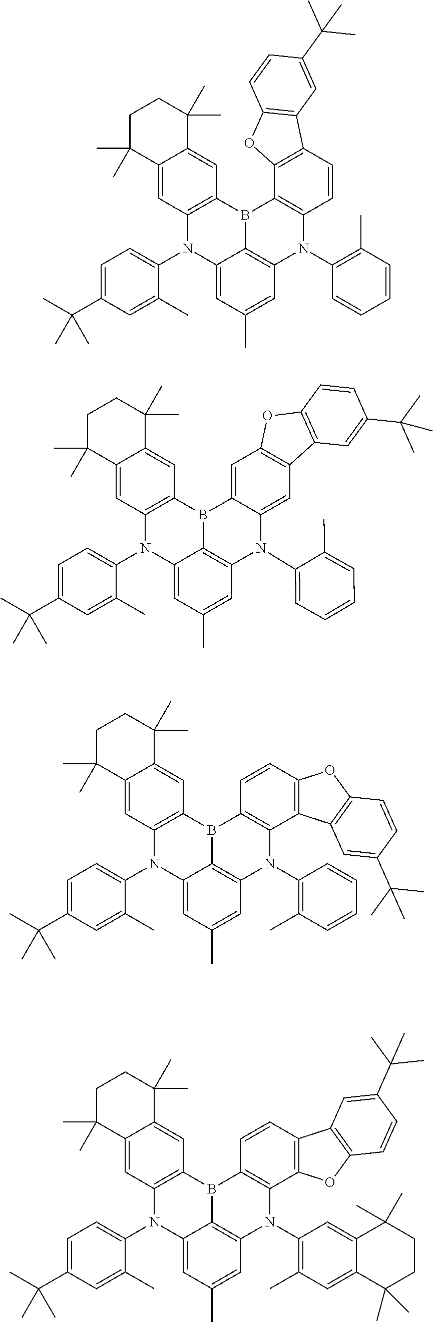

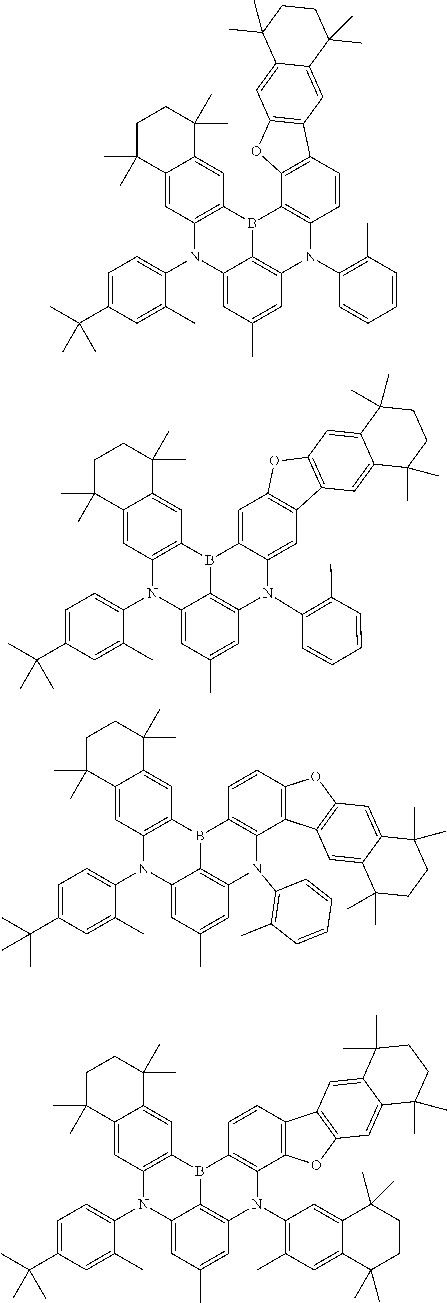

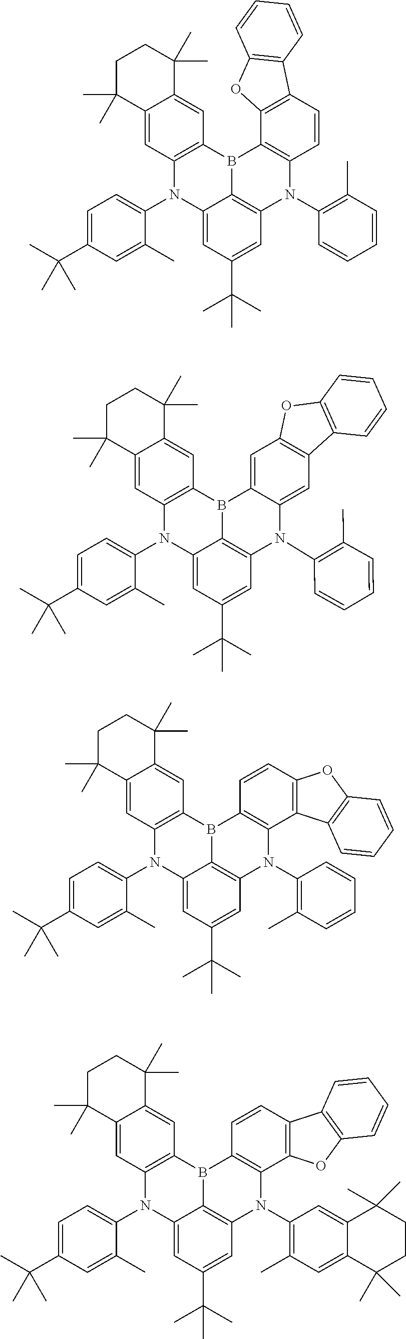 [SMILES: Cc1cc(C(C)(C)C)ccc1N1c2cc3c(cc2B2c4c1cc(C(C)(C)C)cc4N(c1ccccc1C)c1ccc4c(oc5ccccc54)c12)C(C)(C)CCC3(C)C ; Cc1cc(C(C)(C)C)ccc1N1c2cc3c(cc2B2c4cc5oc6ccccc6c5cc4N(c4ccccc4C)c4cc(C(C)(C)C)cc1c42)C(C)(C)CCC3(C)C ; Cc1cc(C(C)(C)C)ccc1N1c2cc3c(cc2B2c4ccc5oc6ccccc6c5c4N(c4ccccc4C)c4cc(C(C)(C)C)cc1c42)C(C)(C)CCC3(C)C ; Cc1cc(C(C)(C)C)ccc1N1c2cc3c(cc2B2c4ccc5c(oc6ccccc65)c4N(c4cc5c(cc4C)C(C)(C)CCC5(C)C)c4cc(C(C)(C)C)cc1c42)C(C)(C)CCC3(C)C]

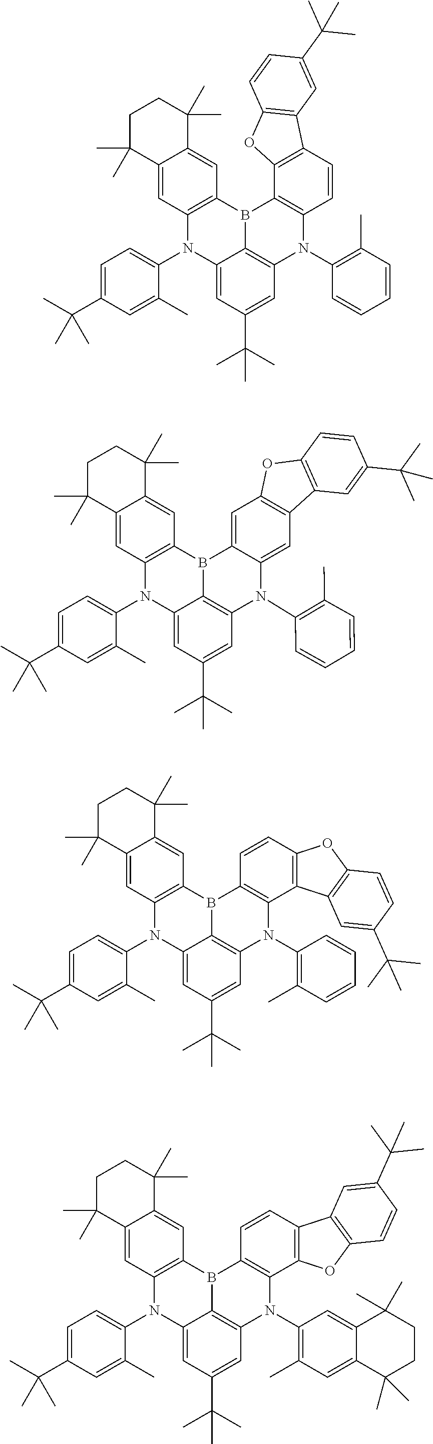

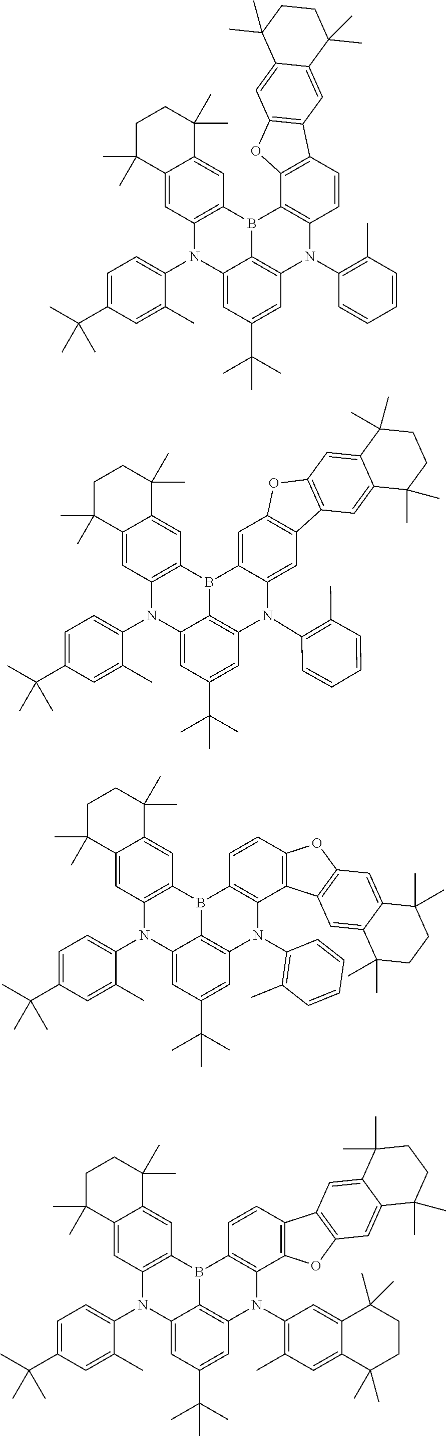

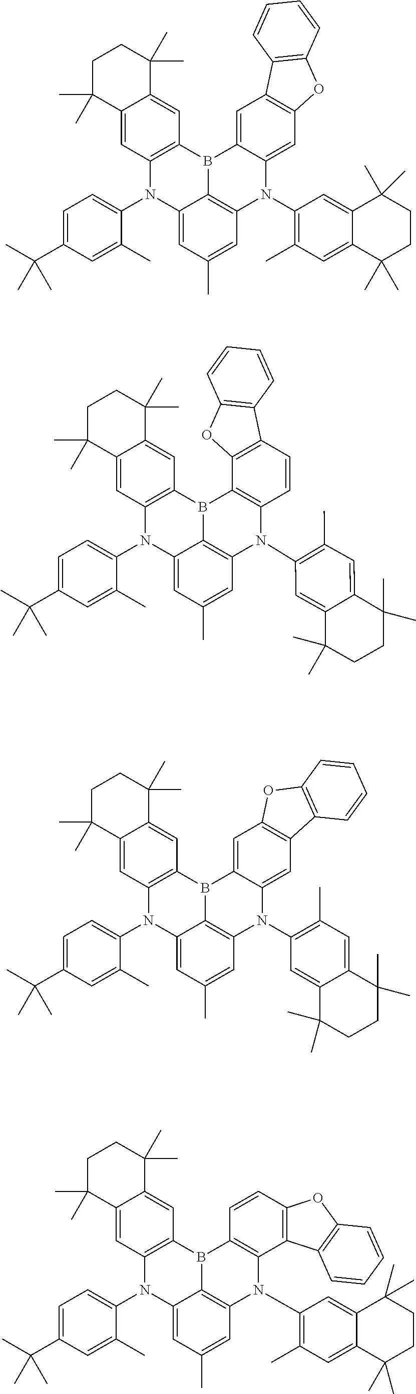

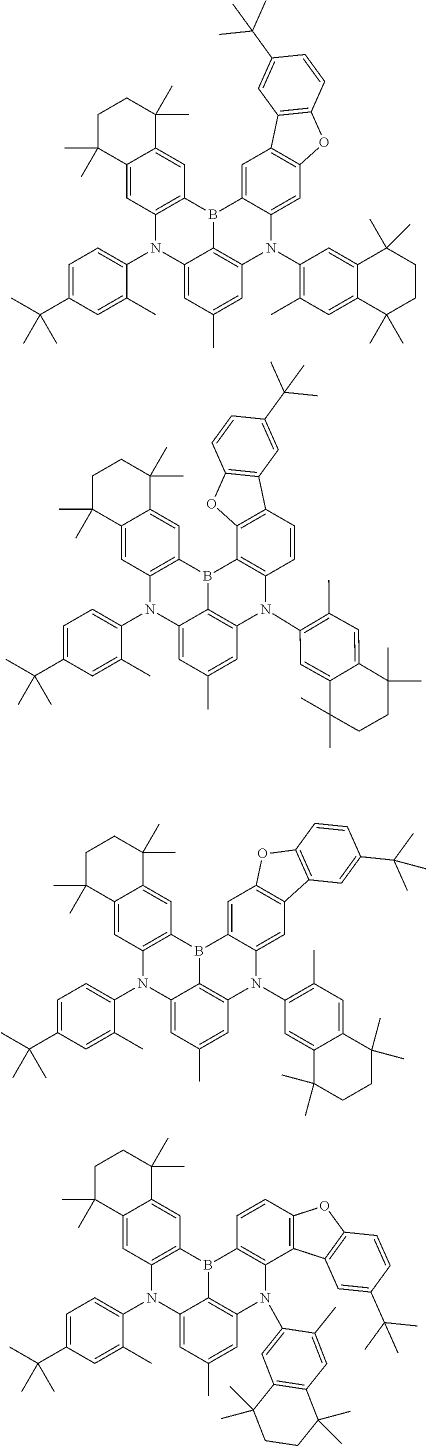

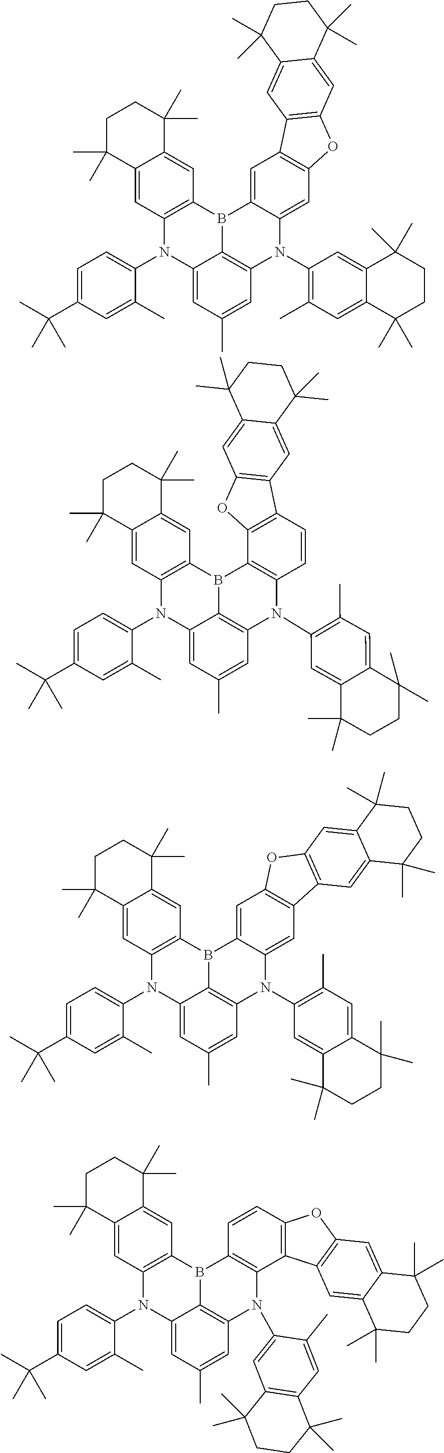

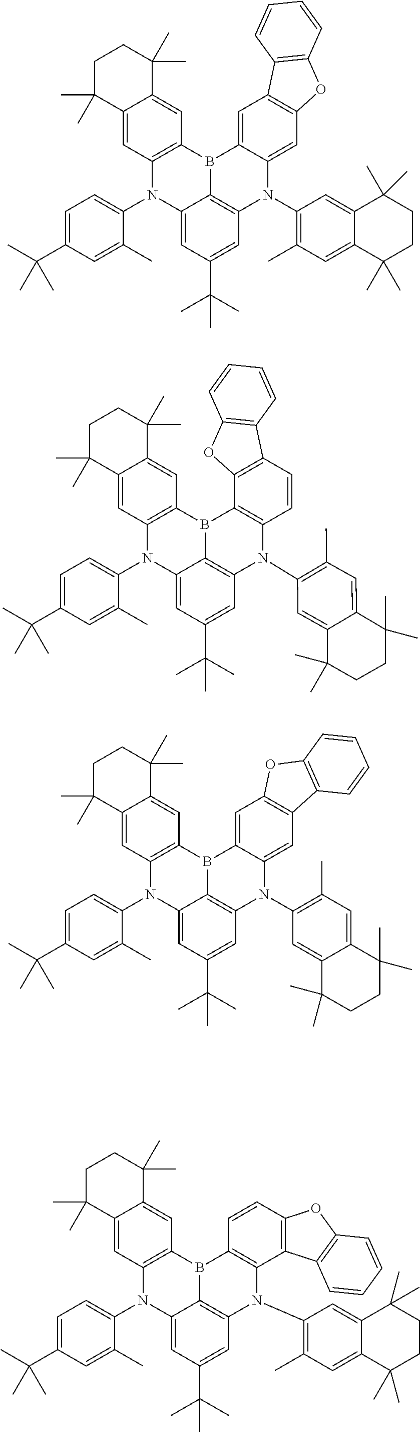

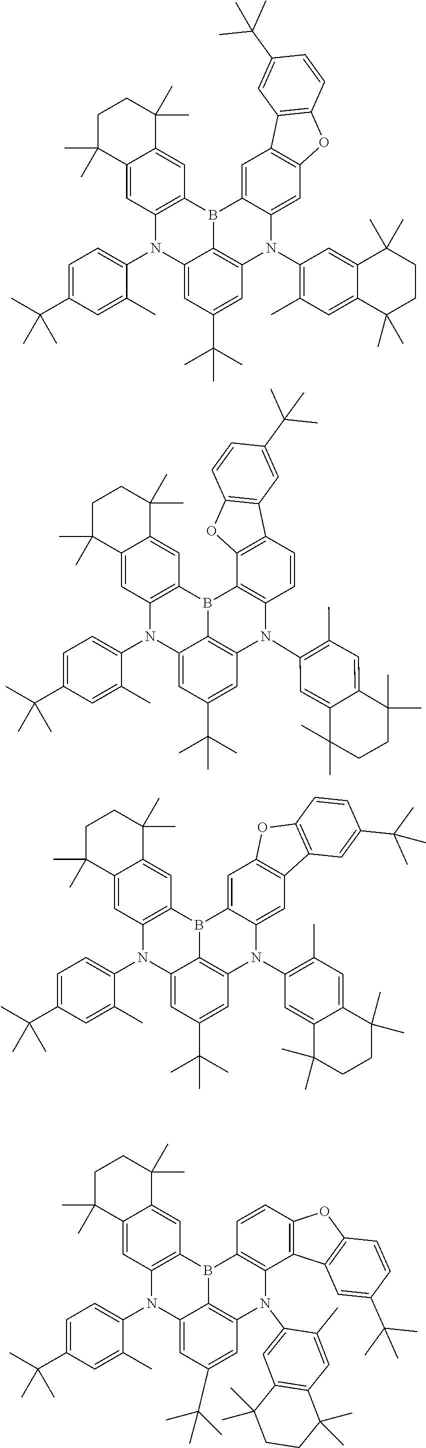

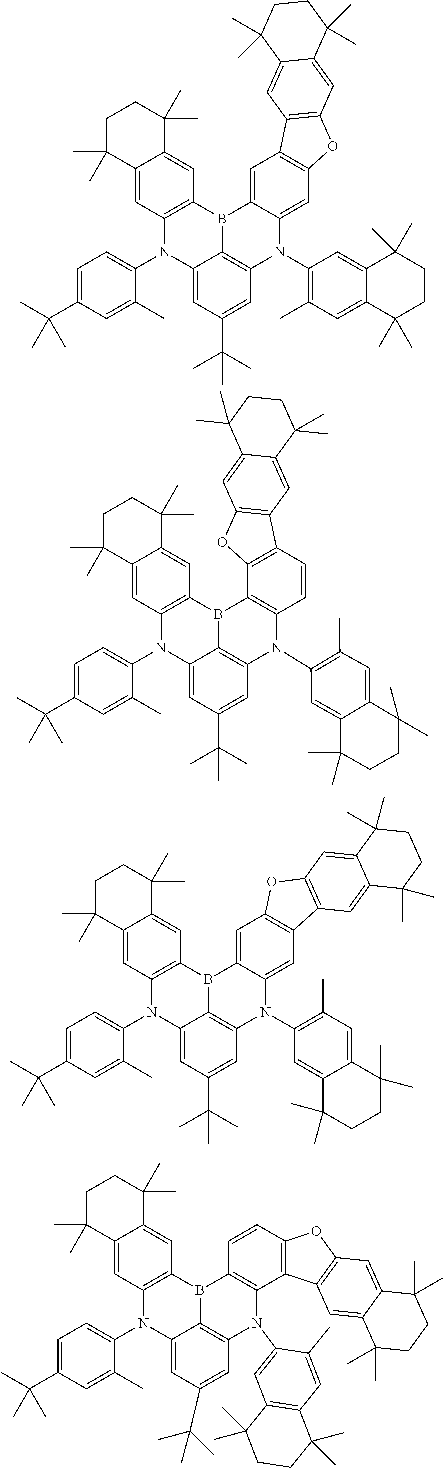

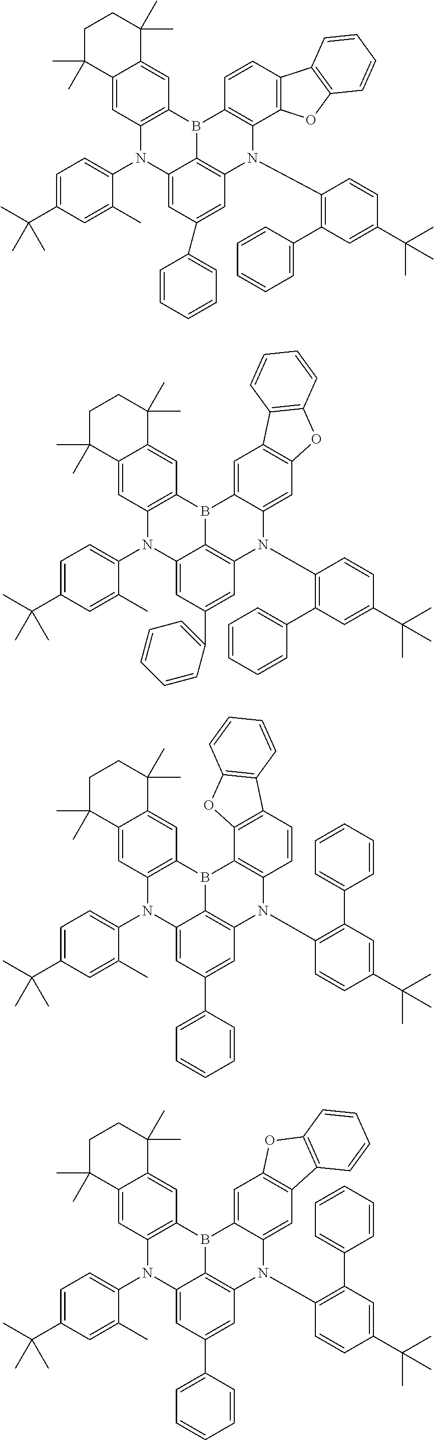

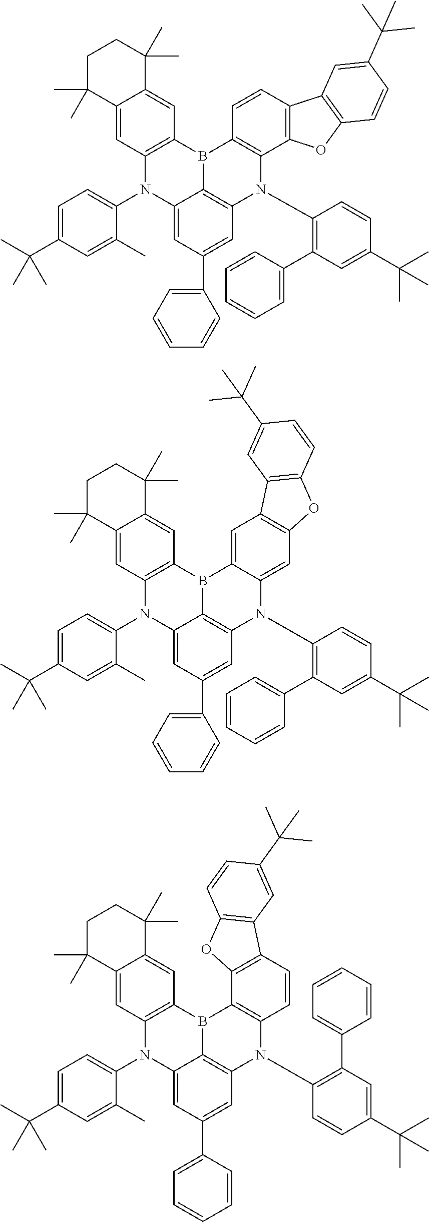

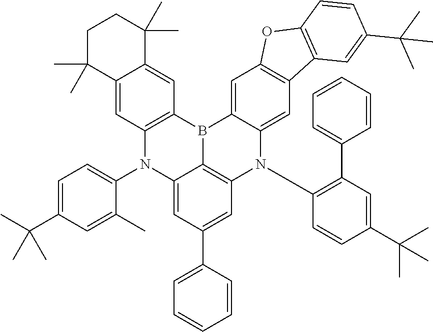 [SMILES: Cc1cc(C(C)(C)C)ccc1N1c2cc3c(cc2B2c4cc5oc6ccc(C(C)(C)C)cc6c5cc4N(c4ccc(C(C)(C)C)cc4-c4ccccc4)c4cc(-c5ccccc5)cc1c42)C(C)(C)CCC3(C)C]

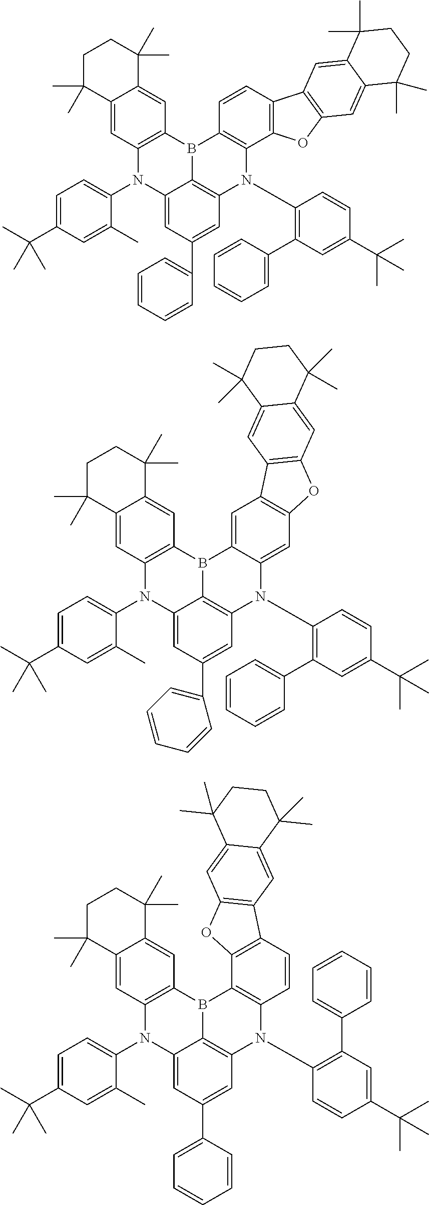

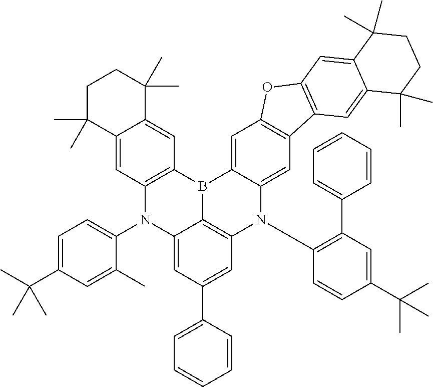 [SMILES: Cc1cc(C(C)(C)C)ccc1N1c2cc3c(cc2B2c4cc5oc6cc7c(cc6c5cc4N(c4ccc(C(C)(C)C)cc4-c4ccccc4)c4cc(-c5ccccc5)cc1c42)C(C)(C)CCC7(C)C)C(C)(C)CCC3(C)C]

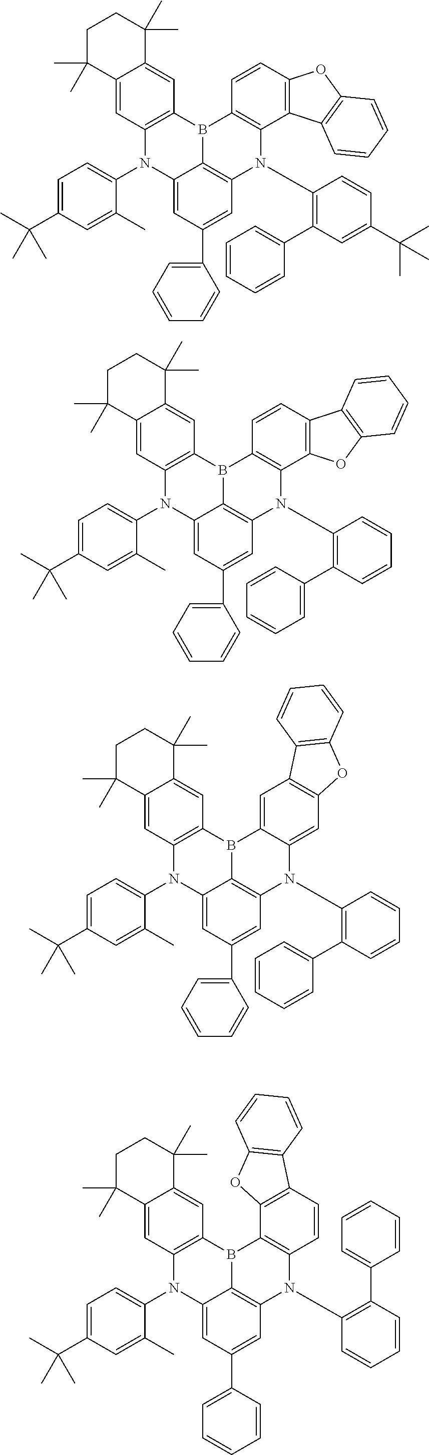

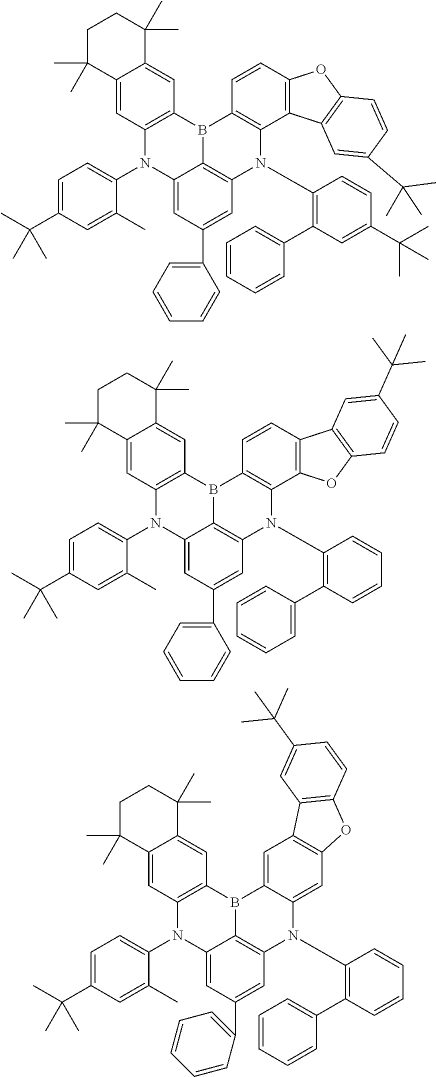

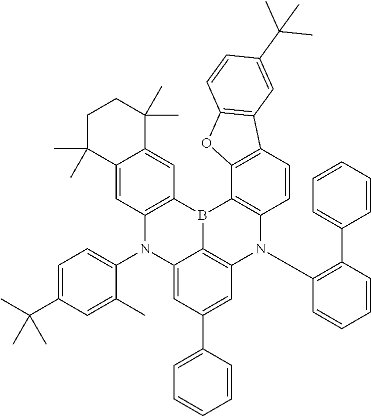 [SMILES: Cc1cc(C(C)(C)C)ccc1N1c2cc3c(cc2B2c4c1cc(-c1ccccc1)cc4N(c1ccccc1-c1ccccc1)c1ccc4c(oc5ccc(C(C)(C)C)cc54)c12)C(C)(C)CCC3(C)C]

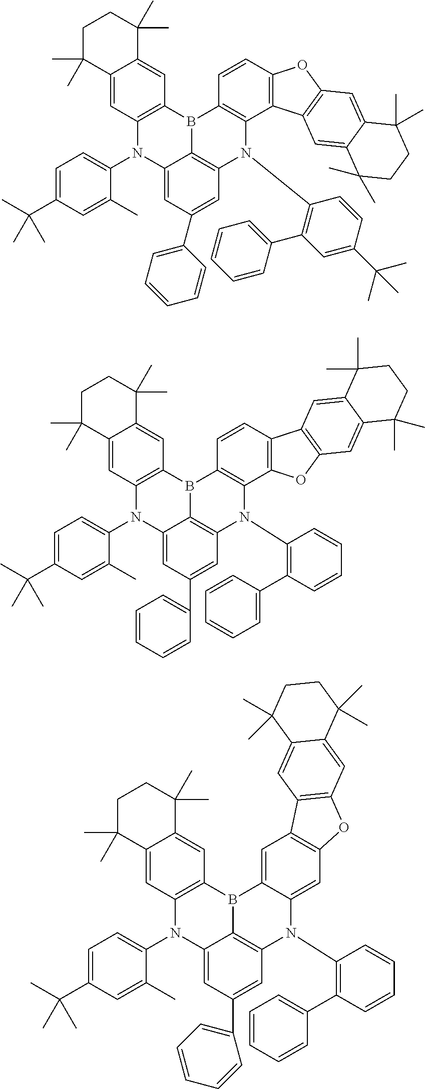

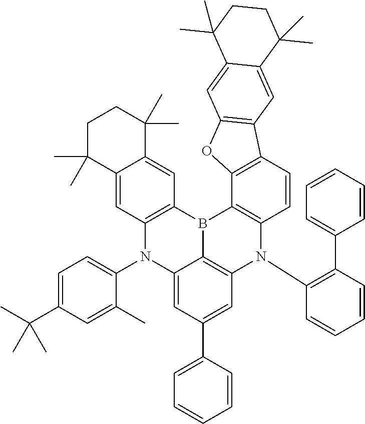 [SMILES: Cc1cc(C(C)(C)C)ccc1N1c2cc3c(cc2B2c4c1cc(-c1ccccc1)cc4N(c1ccccc1-c1ccccc1)c1ccc4c(oc5cc6c(cc54)C(C)(C)CCC6(C)C)c12)C(C)(C)CCC3(C)C]

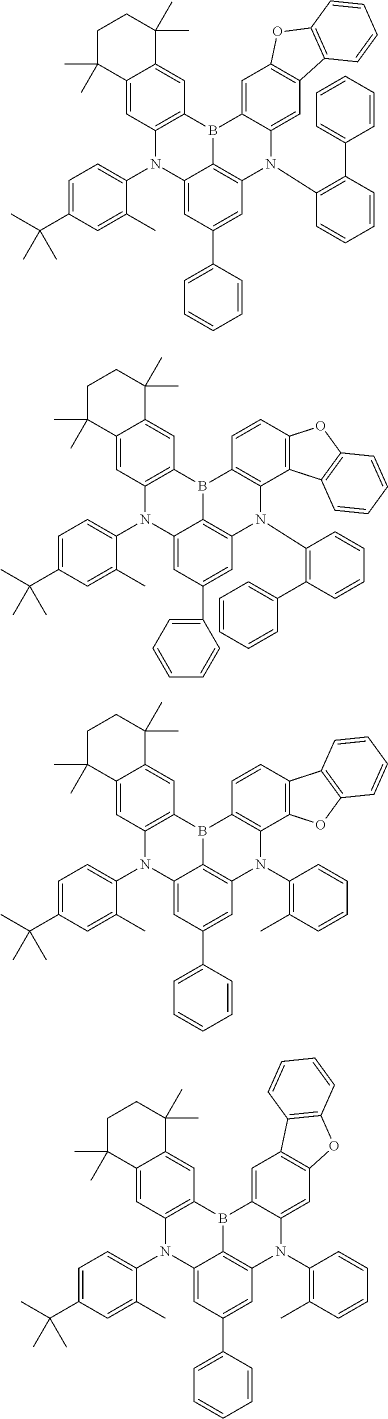

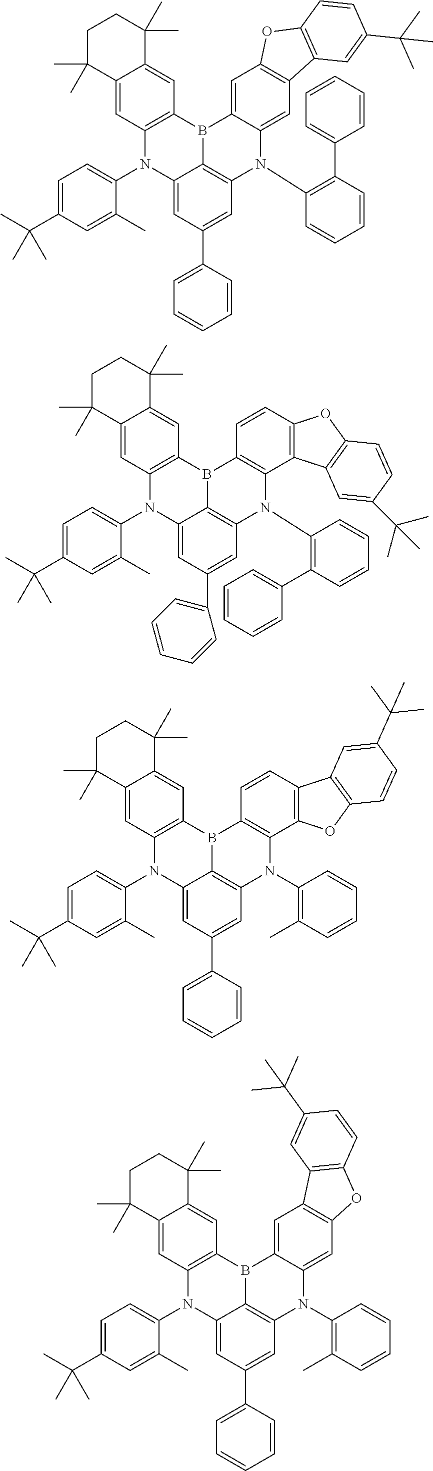

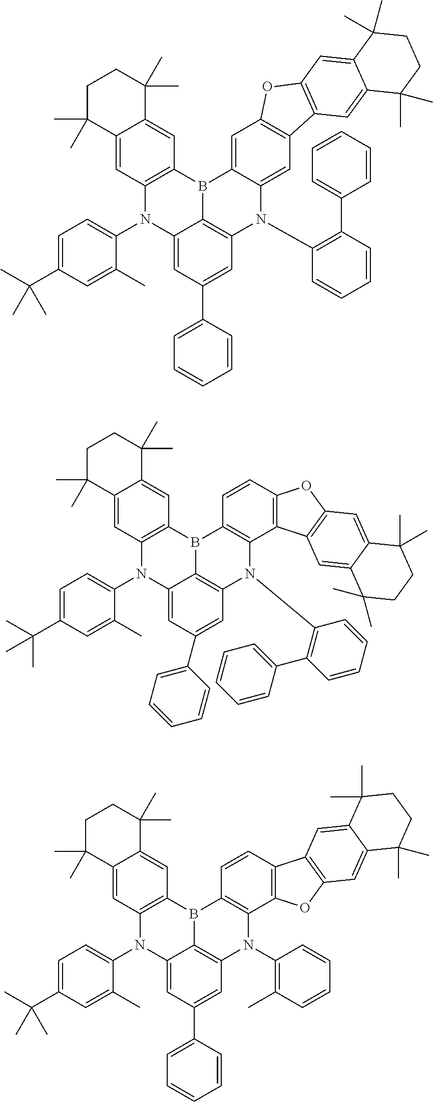

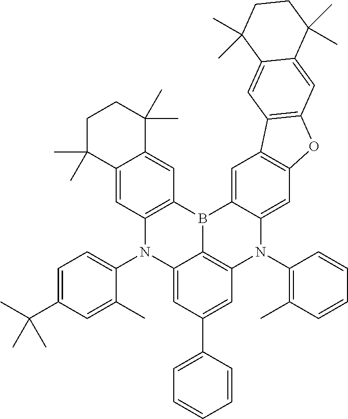 [SMILES: Cc1cc(C(C)(C)C)ccc1N1c2cc3c(cc2B2c4cc5c(cc4N(c4ccccc4C)c4cc(-c6ccccc6)cc1c42)oc1cc2c(cc15)C(C)(C)CCC2(C)C)C(C)(C)CCC3(C)C]

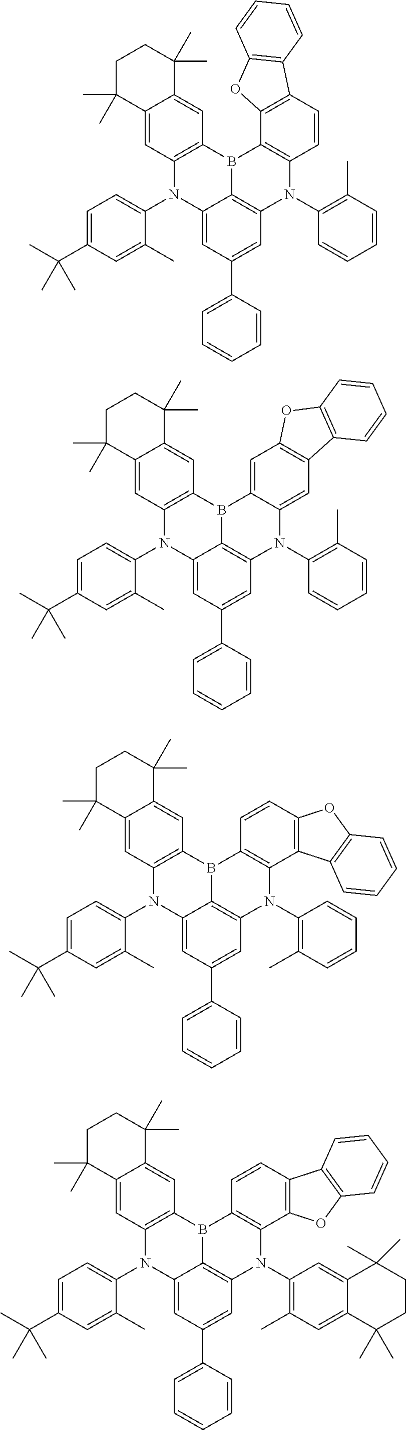

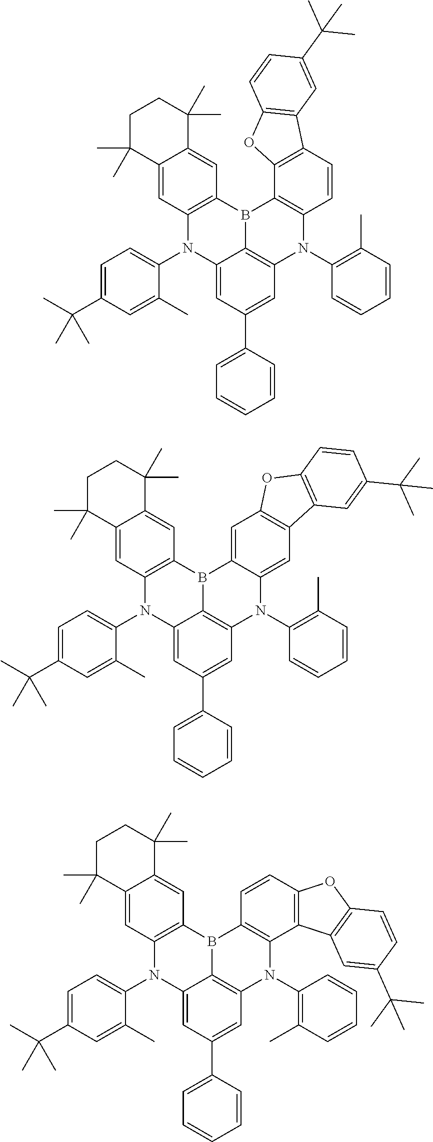

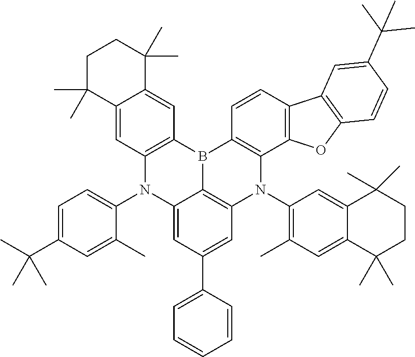 [SMILES: Cc1cc(C(C)(C)C)ccc1N1c2cc3c(cc2B2c4ccc5c(oc6ccc(C(C)(C)C)cc65)c4N(c4cc5c(cc4C)C(C)(C)CCC5(C)C)c4cc(-c5ccccc5)cc1c42)C(C)(C)CCC3(C)C]

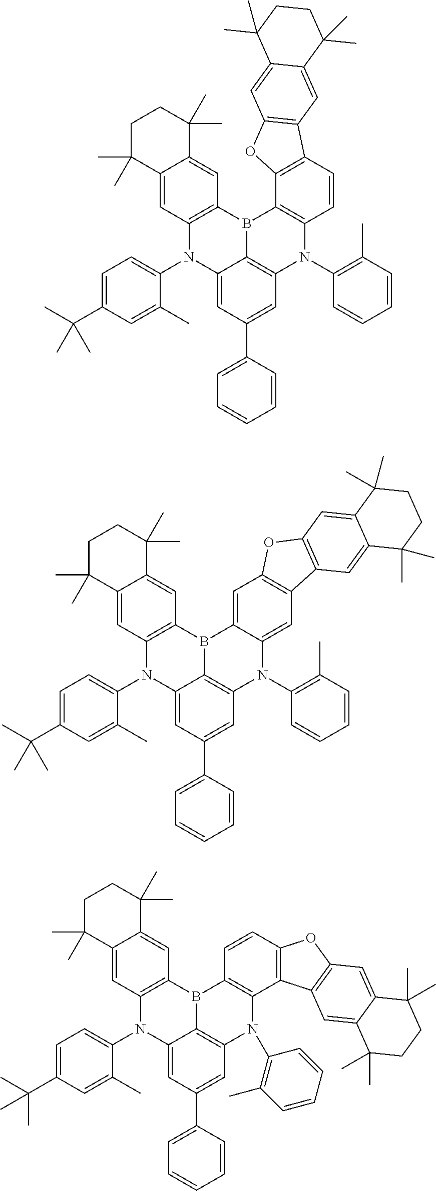

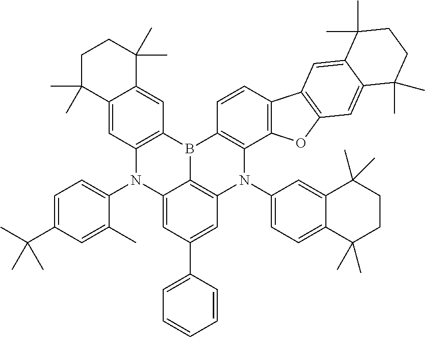 [SMILES: Cc1cc(C(C)(C)C)ccc1N1c2cc3c(cc2B2c4ccc5c(oc6cc7c(cc65)C(C)(C)CCC7(C)C)c4N(c4ccc5c(c4)C(C)(C)CCC5(C)C)c4cc(-c5ccccc5)cc1c42)C(C)(C)CCC3(C)C]

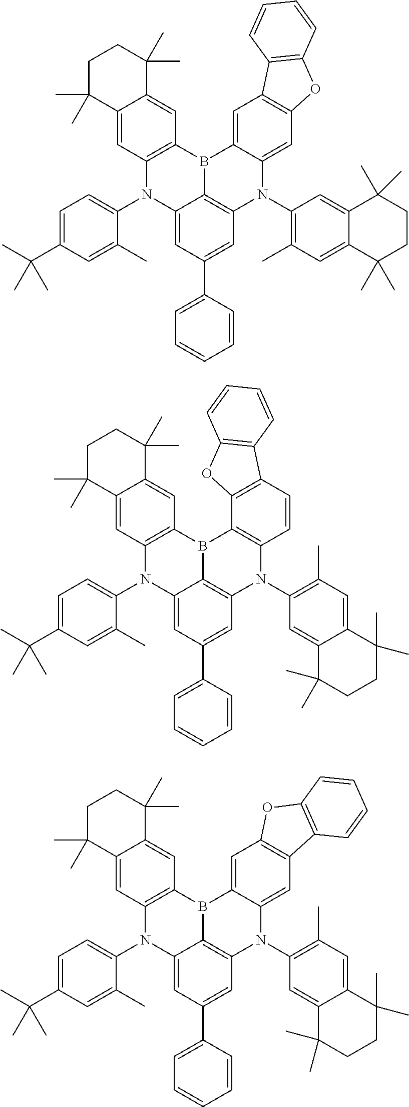

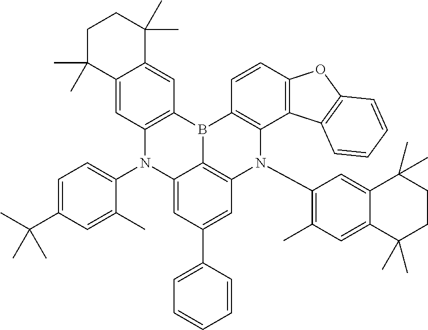 [SMILES: Cc1cc(C(C)(C)C)ccc1N1c2cc3c(cc2B2c4ccc5oc6ccccc6c5c4N(c4cc5c(cc4C)C(C)(C)CCC5(C)C)c4cc(-c5ccccc5)cc1c42)C(C)(C)CCC3(C)C]

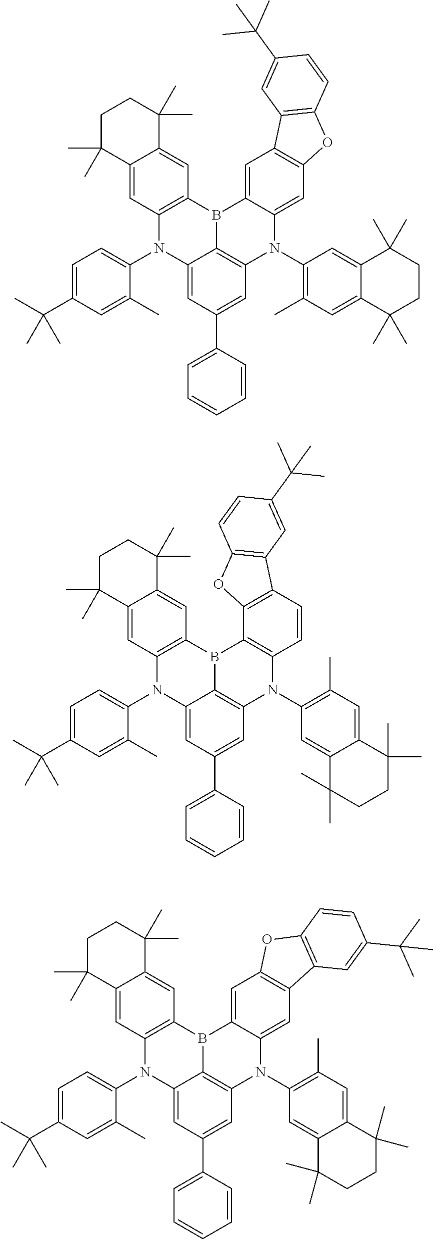

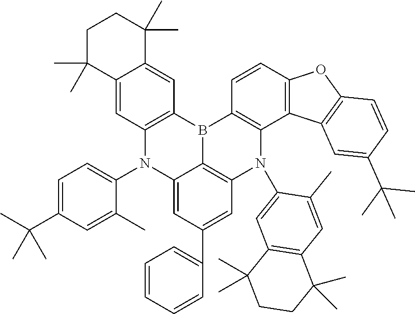 [SMILES: Cc1cc(C(C)(C)C)ccc1N1c2cc3c(cc2B2c4ccc5oc6ccc(C(C)(C)C)cc6c5c4N(c4cc5c(cc4C)C(C)(C)CCC5(C)C)c4cc(-c5ccccc5)cc1c42)C(C)(C)CCC3(C)C]

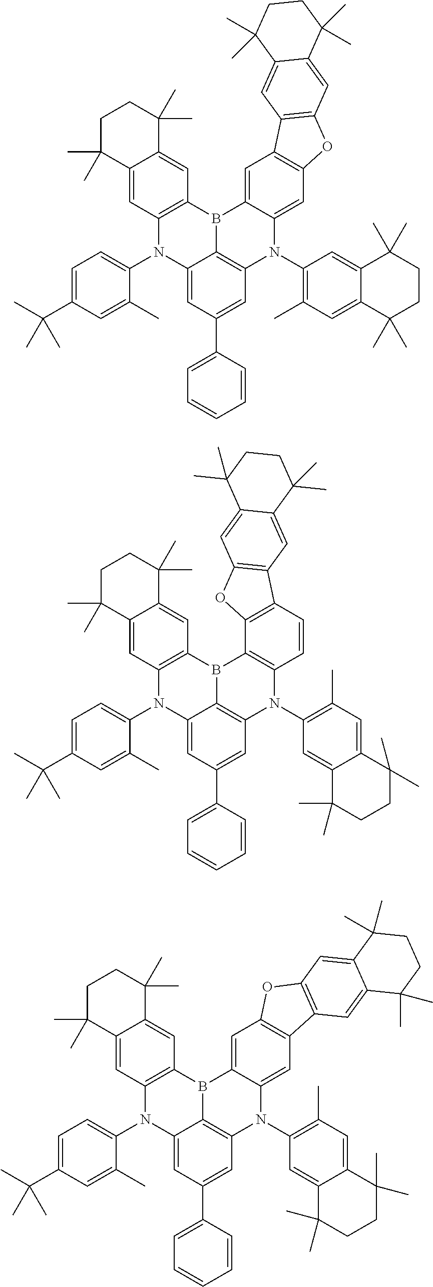

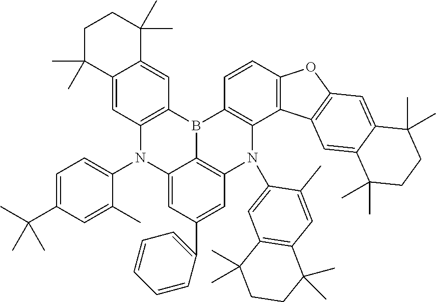 [SMILES: Cc1cc(C(C)(C)C)ccc1N1c2cc3c(cc2B2c4ccc5oc6cc7c(cc6c5c4N(c4cc5c(cc4C)C(C)(C)CCC5(C)C)c4cc(-c5ccccc5)cc1c42)C(C)(C)CCC7(C)C)C(C)(C)CCC3(C)C]

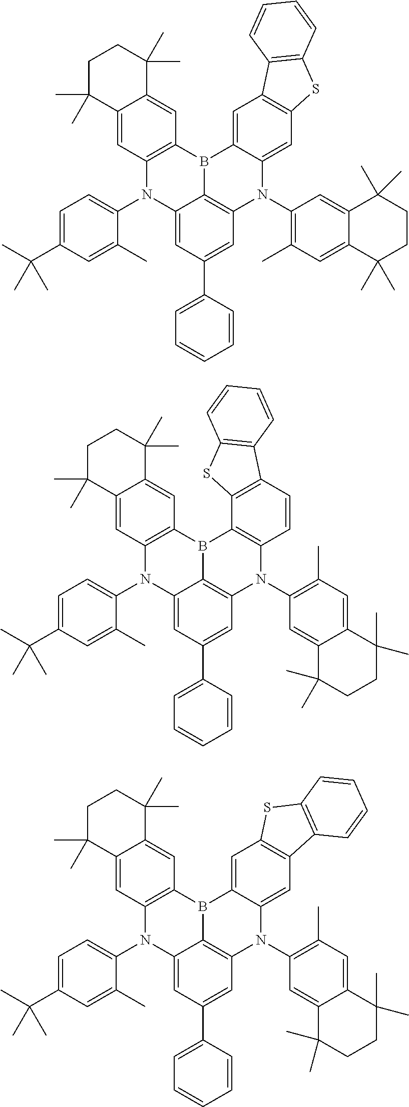

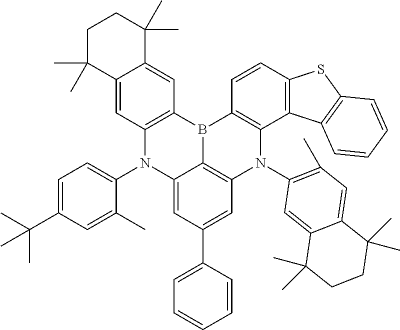 [SMILES: Cc1cc(C(C)(C)C)ccc1N1c2cc3c(cc2B2c4ccc5sc6ccccc6c5c4N(c4cc5c(cc4C)C(C)(C)CCC5(C)C)c4cc(-c5ccccc5)cc1c42)C(C)(C)CCC3(C)C]

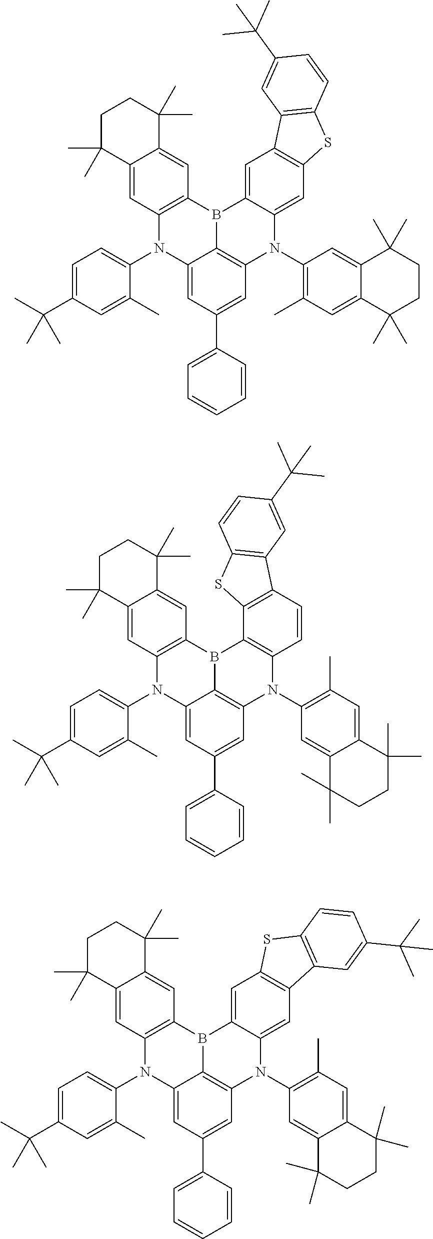

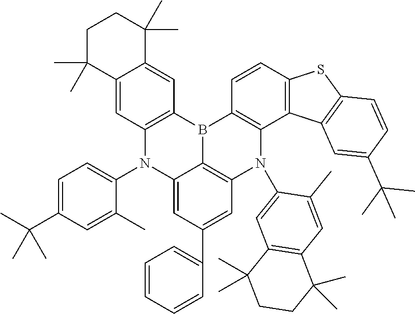 [SMILES: Cc1cc(C(C)(C)C)ccc1N1c2cc3c(cc2B2c4ccc5sc6ccc(C(C)(C)C)cc6c5c4N(c4cc5c(cc4C)C(C)(C)CCC5(C)C)c4cc(-c5ccccc5)cc1c42)C(C)(C)CCC3(C)C]

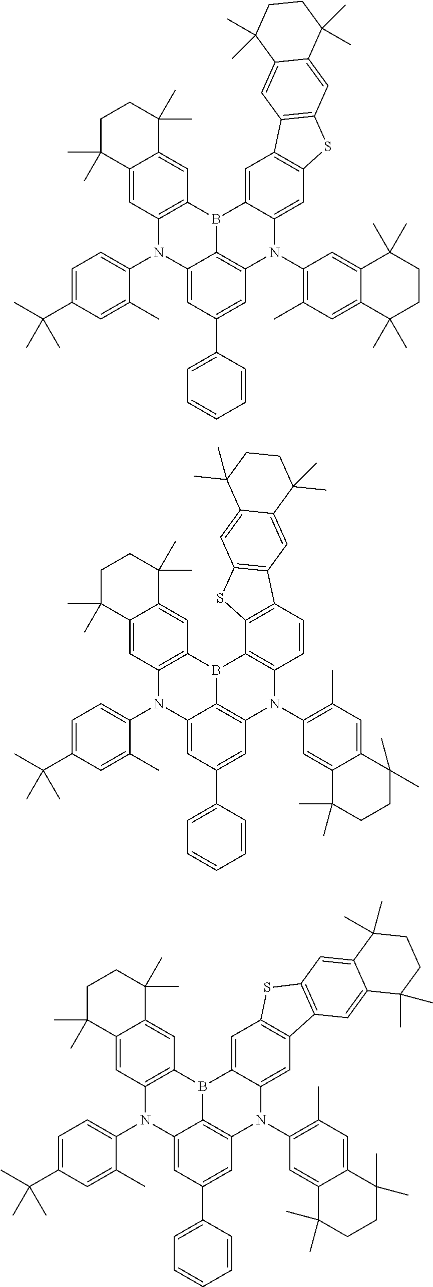

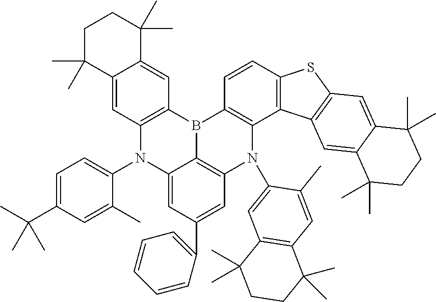 [SMILES: Cc1cc(C(C)(C)C)ccc1N1c2cc3c(cc2B2c4ccc5sc6cc7c(cc6c5c4N(c4cc5c(cc4C)C(C)(C)CCC5(C)C)c4cc(-c5ccccc5)cc1c42)C(C)(C)CCC7(C)C)C(C)(C)CCC3(C)C]

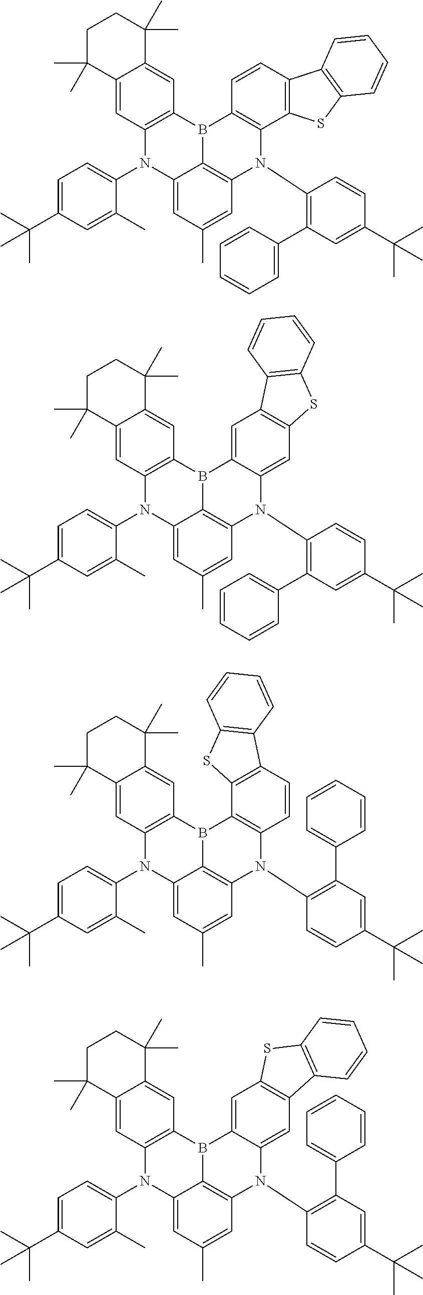

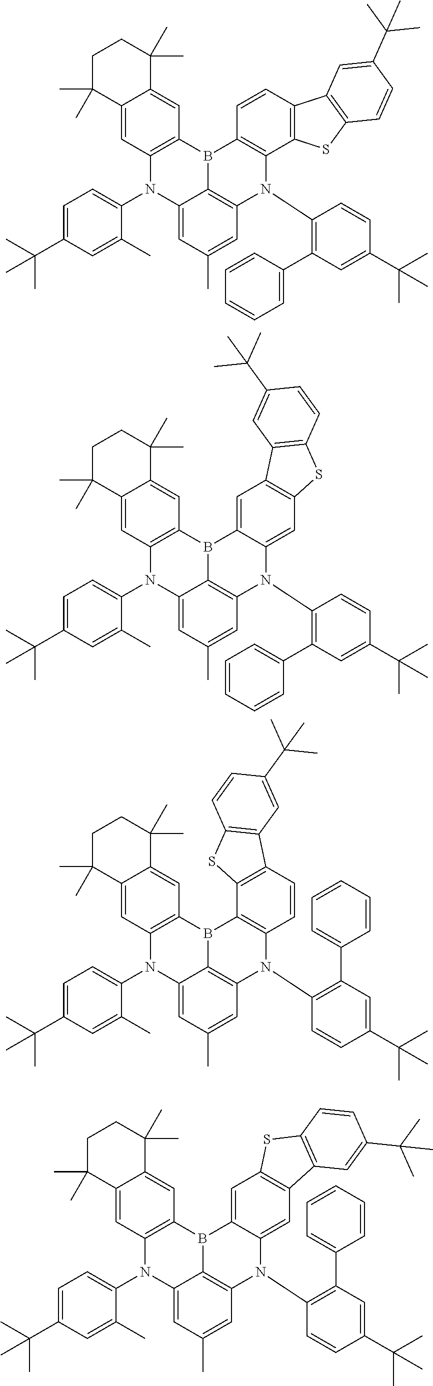

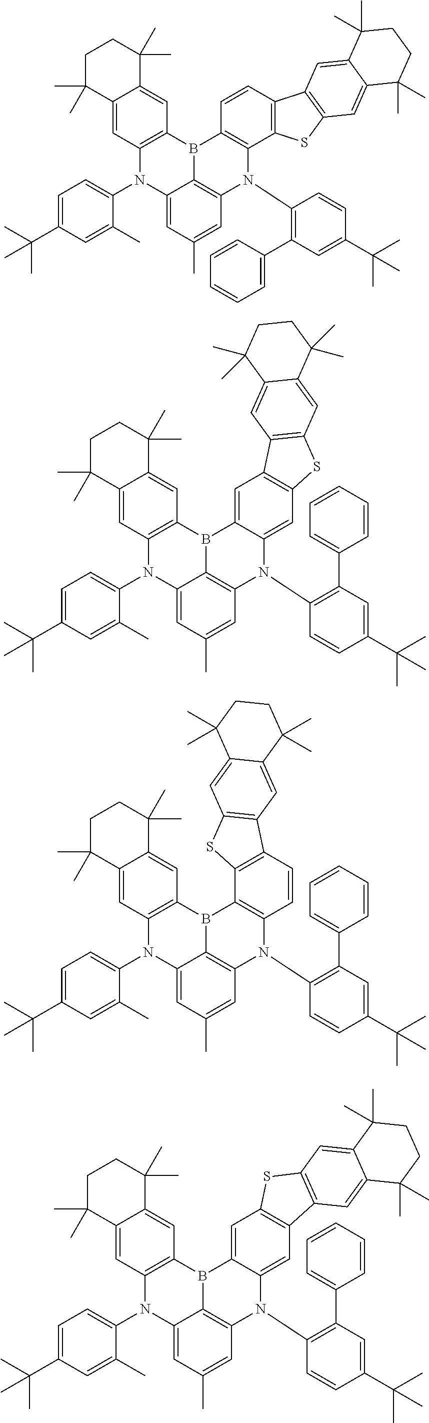

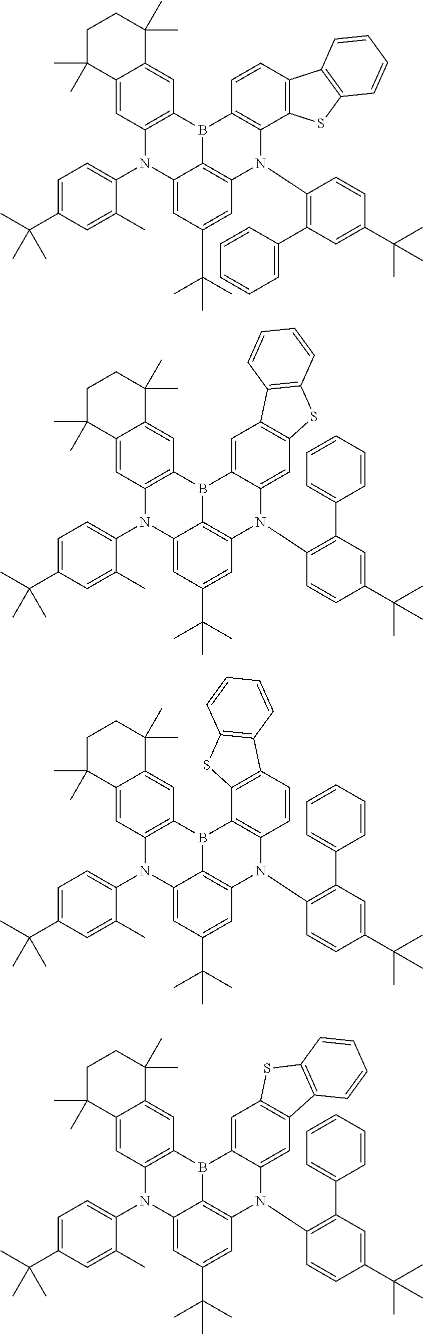

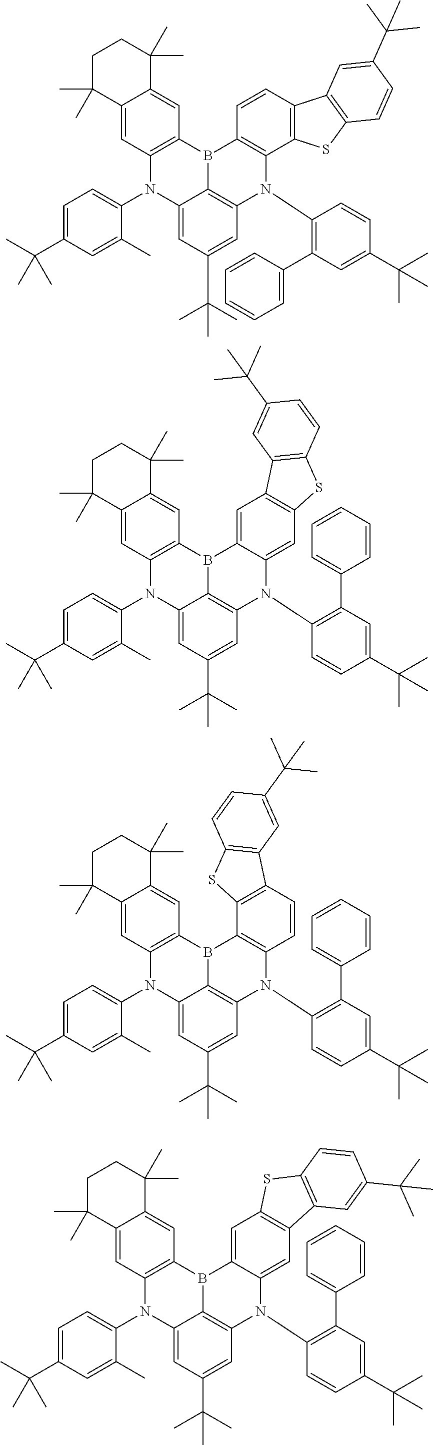

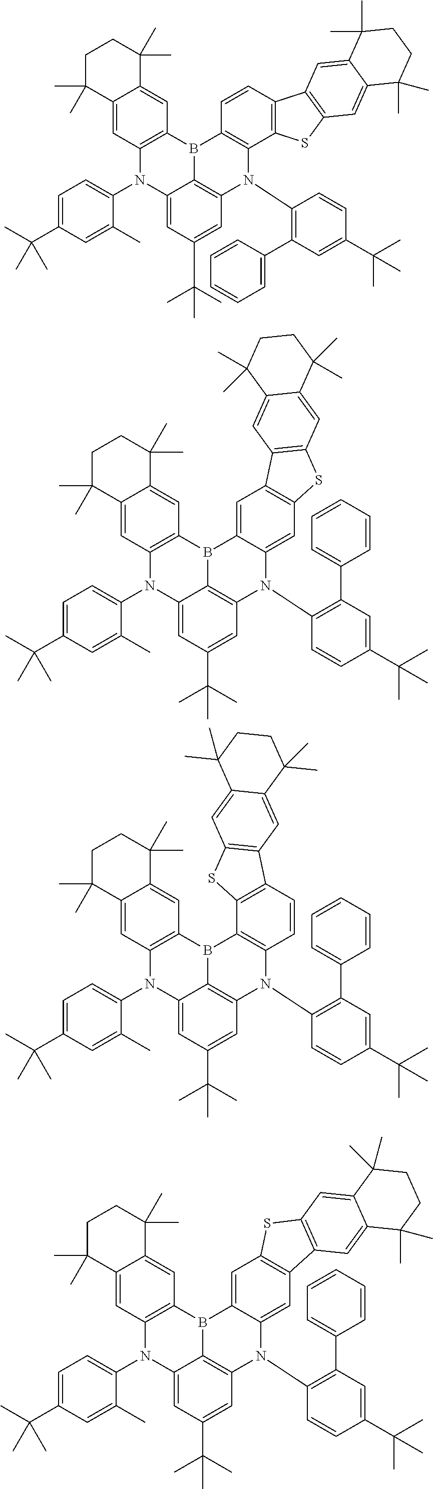

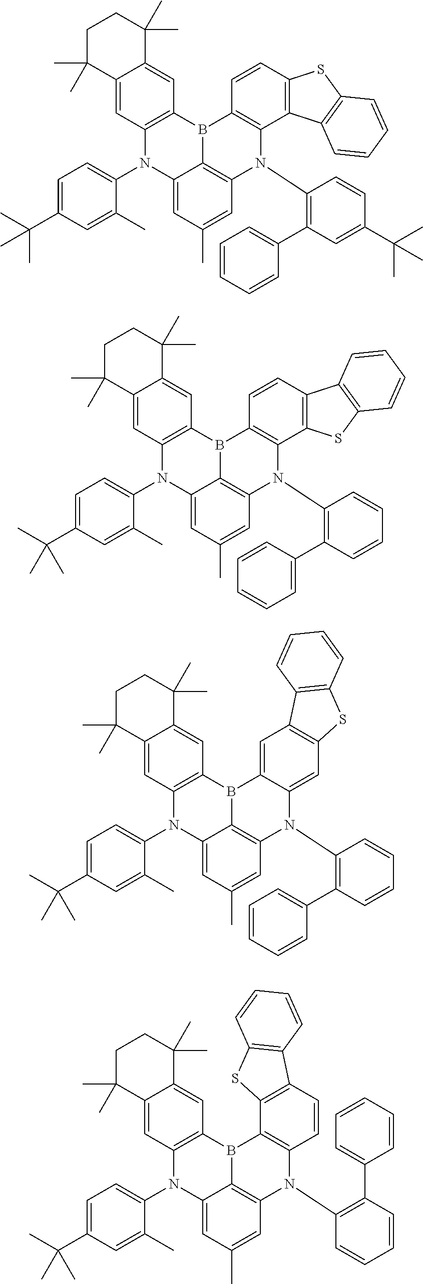

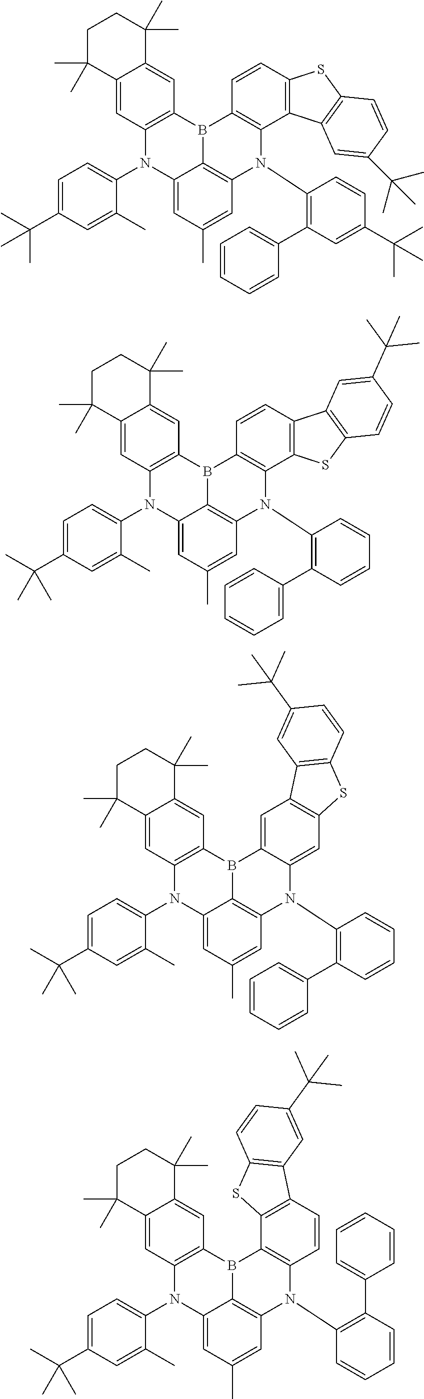

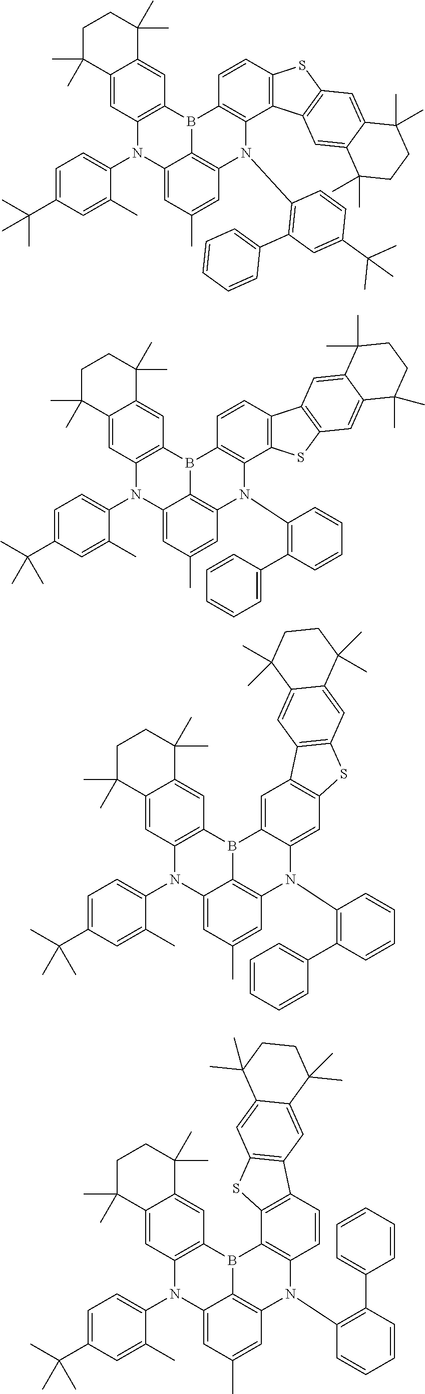

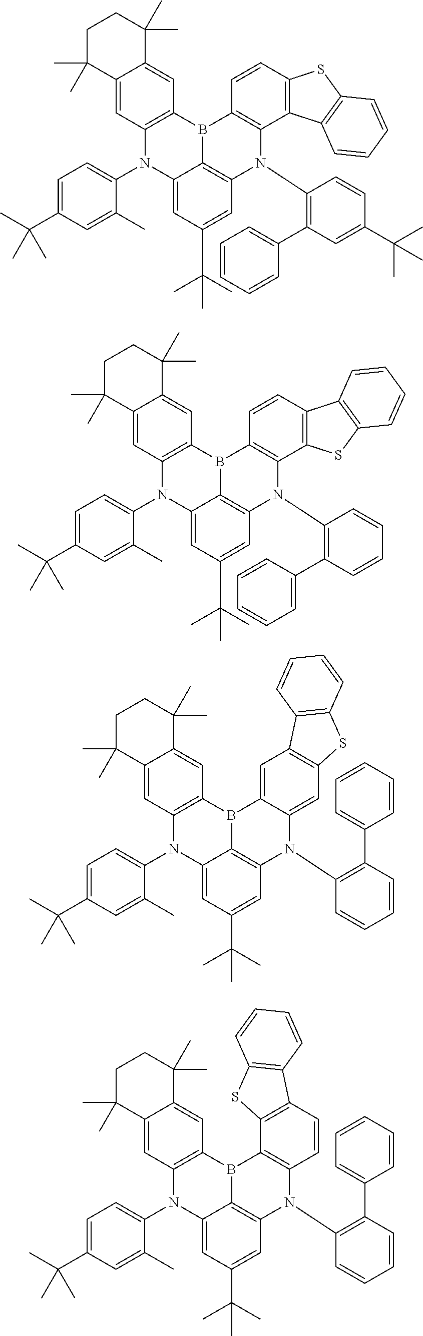

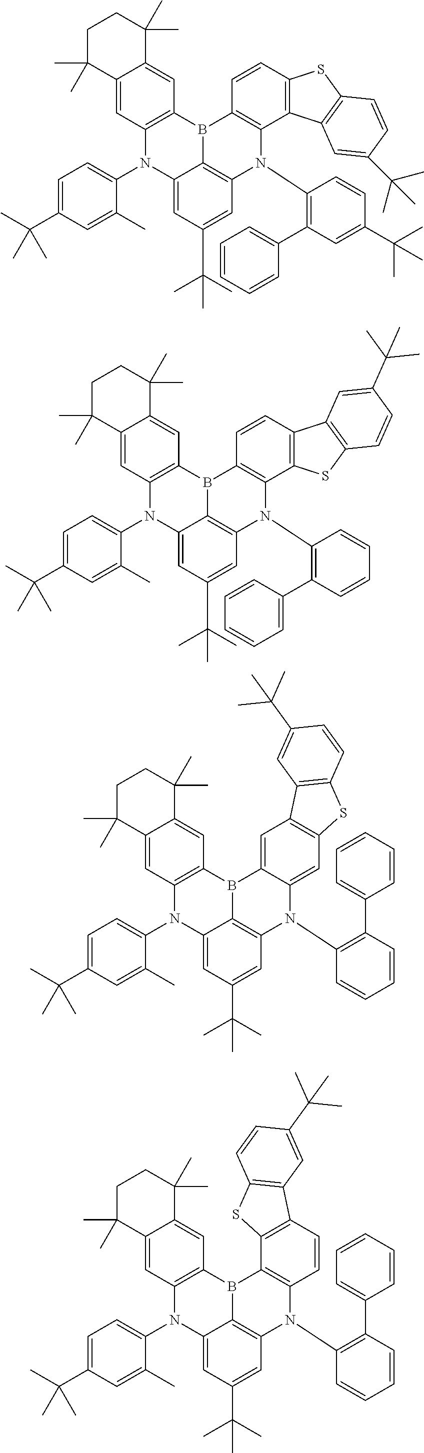

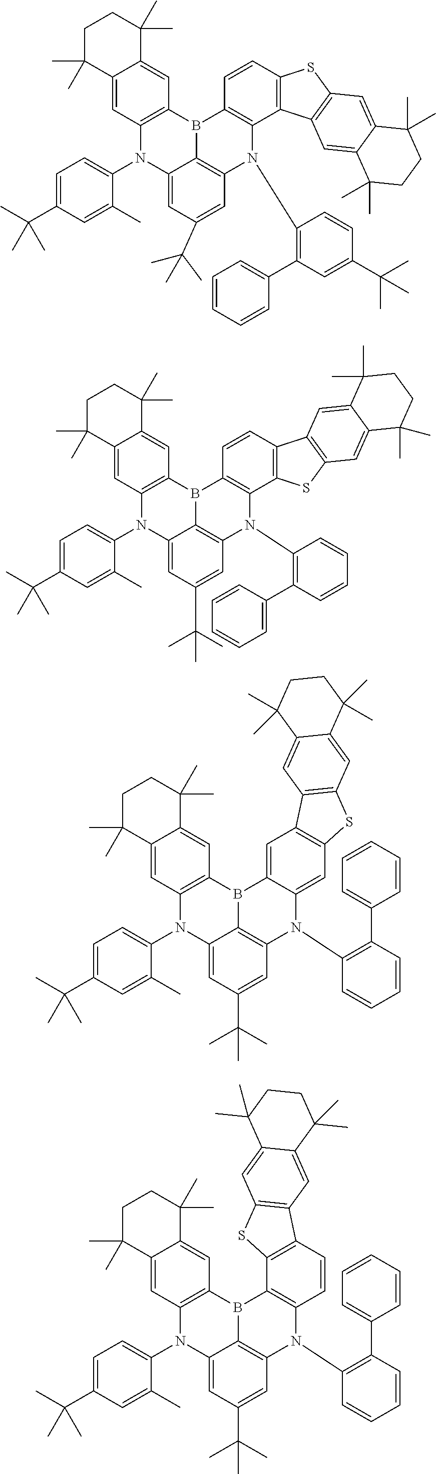

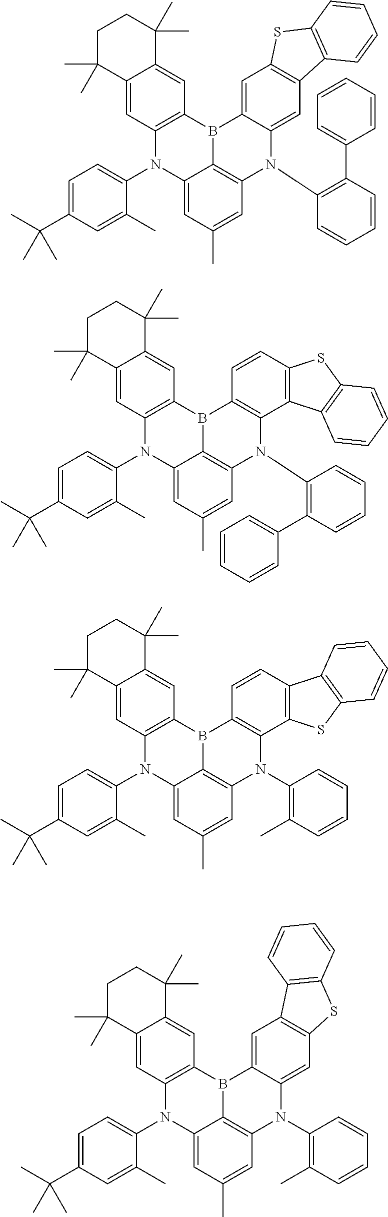 [SMILES: Cc1cc2c3c(c1)N(c1ccccc1-c1ccccc1)c1cc4c(cc1B3c1cc3c(cc1N2c1ccc(C(C)(C)C)cc1C)C(C)(C)CCC3(C)C)sc1ccccc14 ; Cc1cc2c3c(c1)N(c1ccccc1-c1ccccc1)c1c(ccc4sc5ccccc5c14)B3c1cc3c(cc1N2c1ccc(C(C)(C)C)cc1C)C(C)(C)CCC3(C)C ; Cc1cc2c3c(c1)N(c1ccccc1C)c1c(ccc4c1sc1ccccc14)B3c1cc3c(cc1N2c1ccc(C(C)(C)C)cc1C)C(C)(C)CCC3(C)C ; Cc1cc2c3c(c1)N(c1ccccc1C)c1cc4sc5ccccc5c4cc1B3c1cc3c(cc1N2c1ccc(C(C)(C)C)cc1C)C(C)(C)CCC3(C)C]

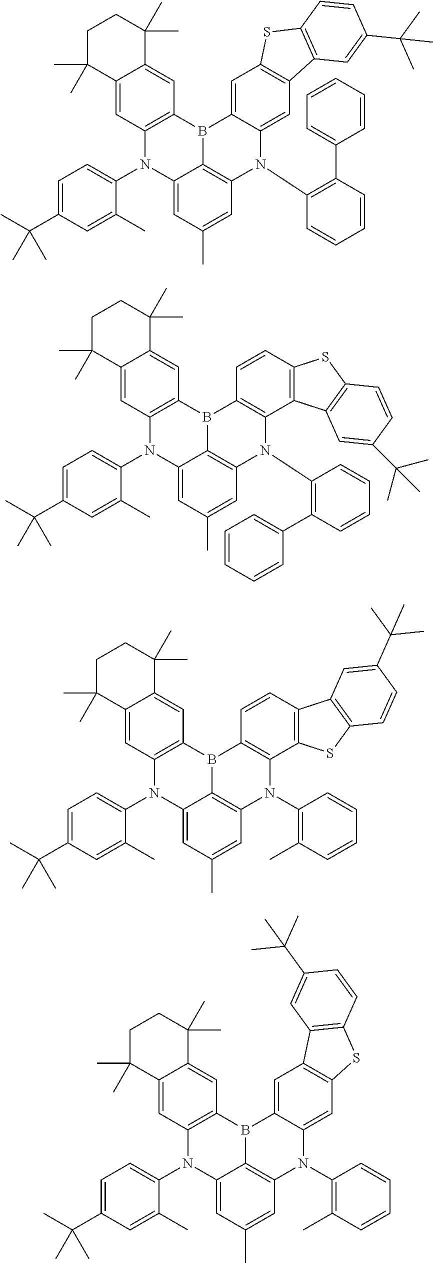

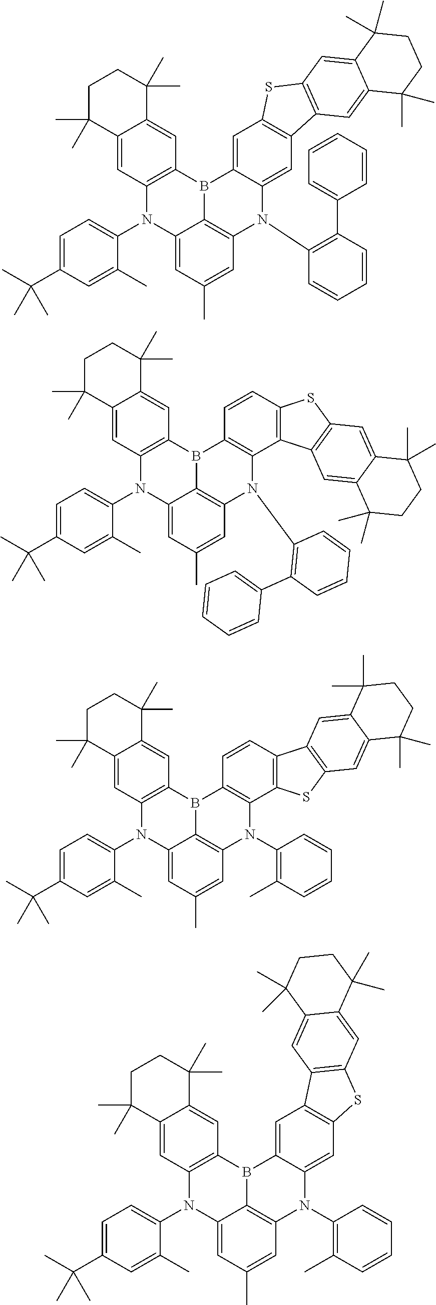

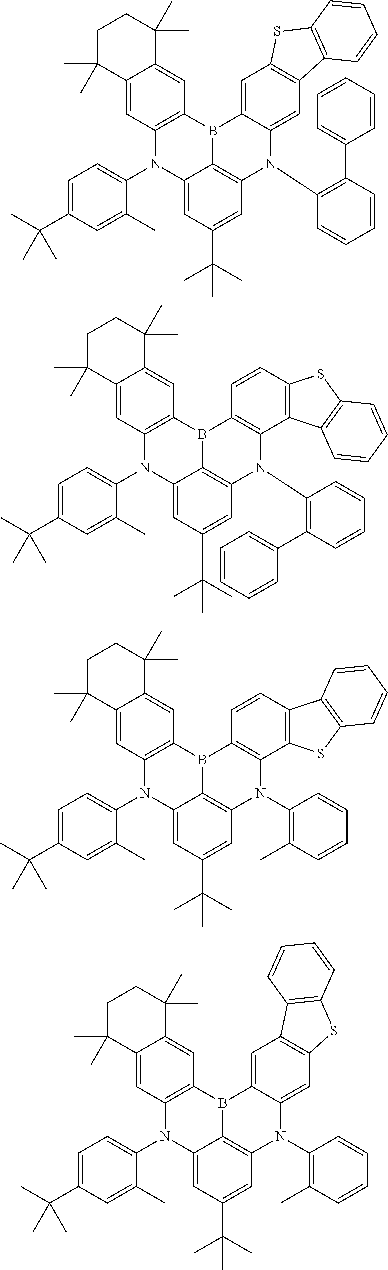

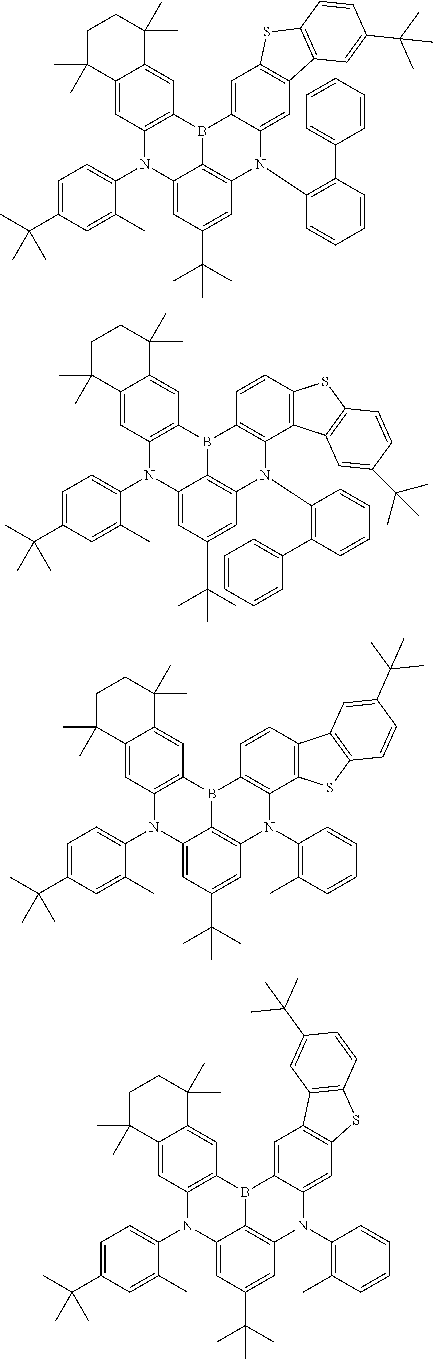

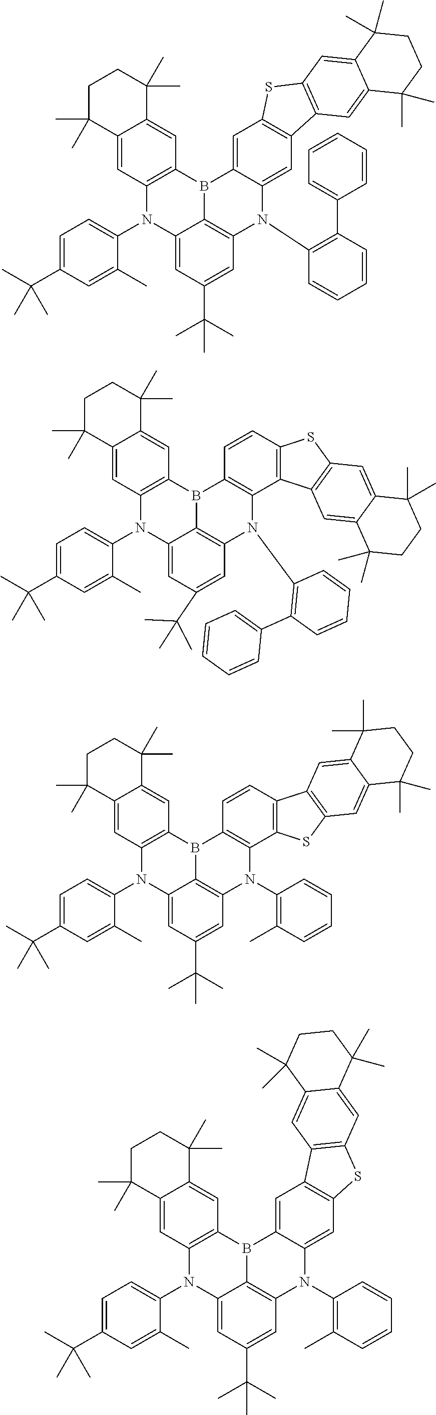

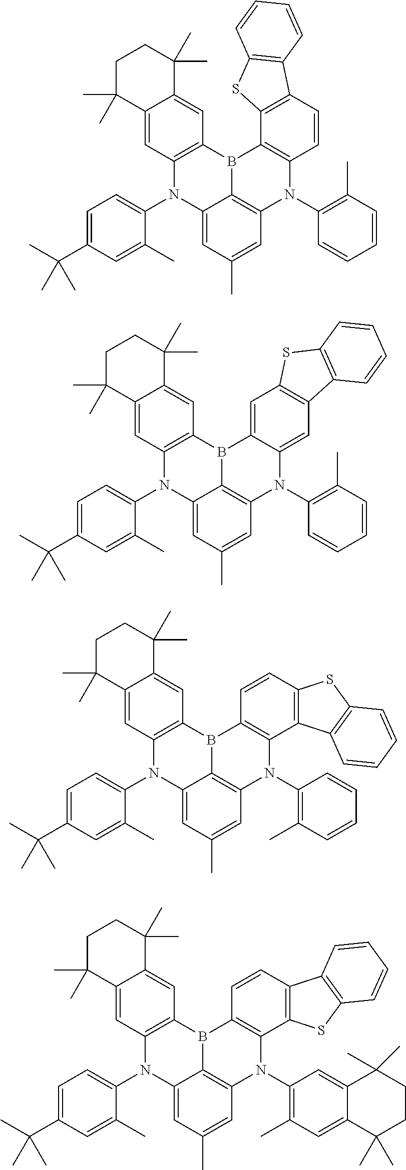 [SMILES: Cc1cc2c3c(c1)N(c1ccccc1C)c1ccc4c(sc5ccccc54)c1B3c1cc3c(cc1N2c1ccc(C(C)(C)C)cc1C)C(C)(C)CCC3(C)C ; Cc1cc2c3c(c1)N(c1ccccc1C)c1cc4c(cc1B3c1cc3c(cc1N2c1ccc(C(C)(C)C)cc1C)C(C)(C)CCC3(C)C)sc1ccccc14 ; Cc1cc2c3c(c1)N(c1ccccc1C)c1c(ccc4sc5ccccc5c14)B3c1cc3c(cc1N2c1ccc(C(C)(C)C)cc1C)C(C)(C)CCC3(C)C ; Cc1cc2c3c(c1)N(c1cc4c(cc1C)C(C)(C)CCC4(C)C)c1c(ccc4c1sc1ccccc14)B3c1cc3c(cc1N2c1ccc(C(C)(C)C)cc1C)C(C)(C)CCC3(C)C]

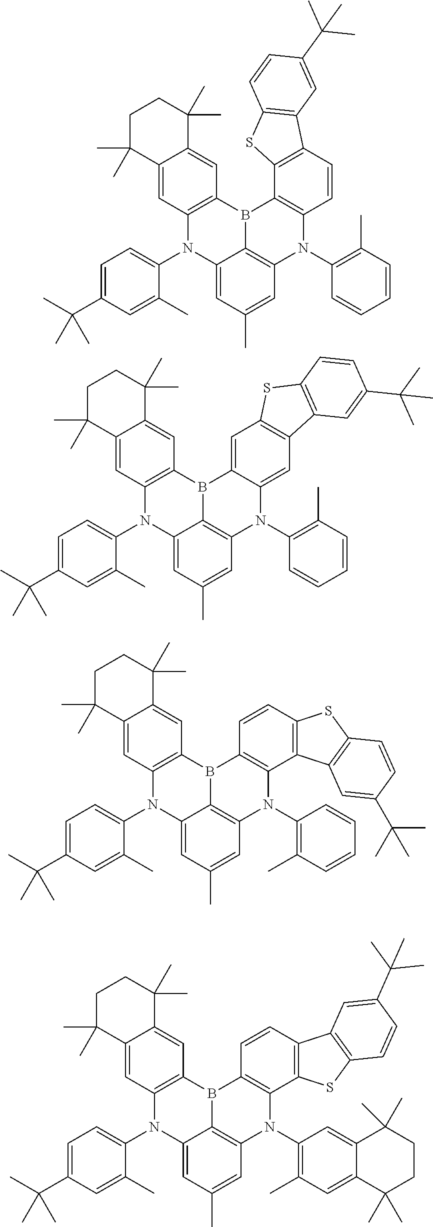

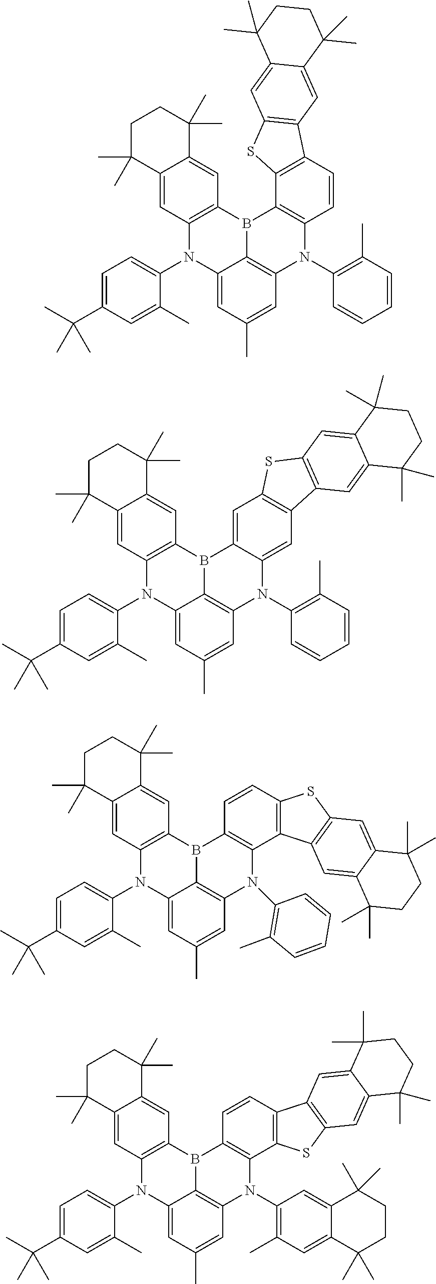

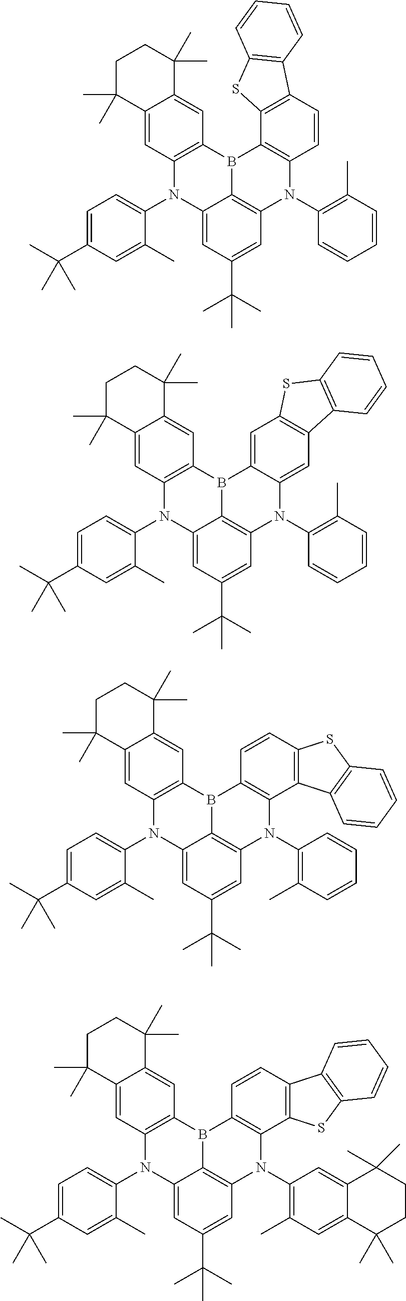

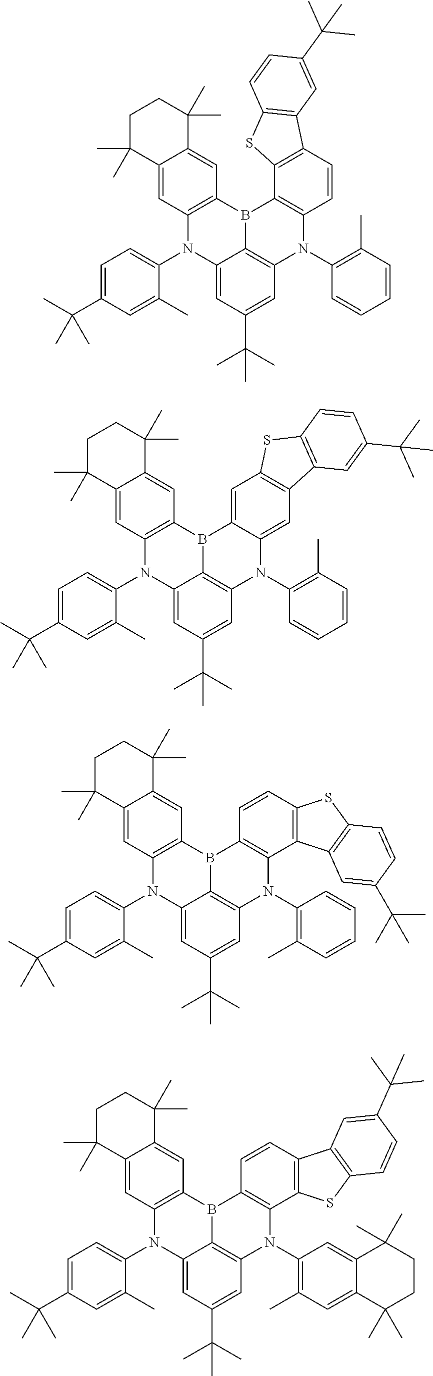

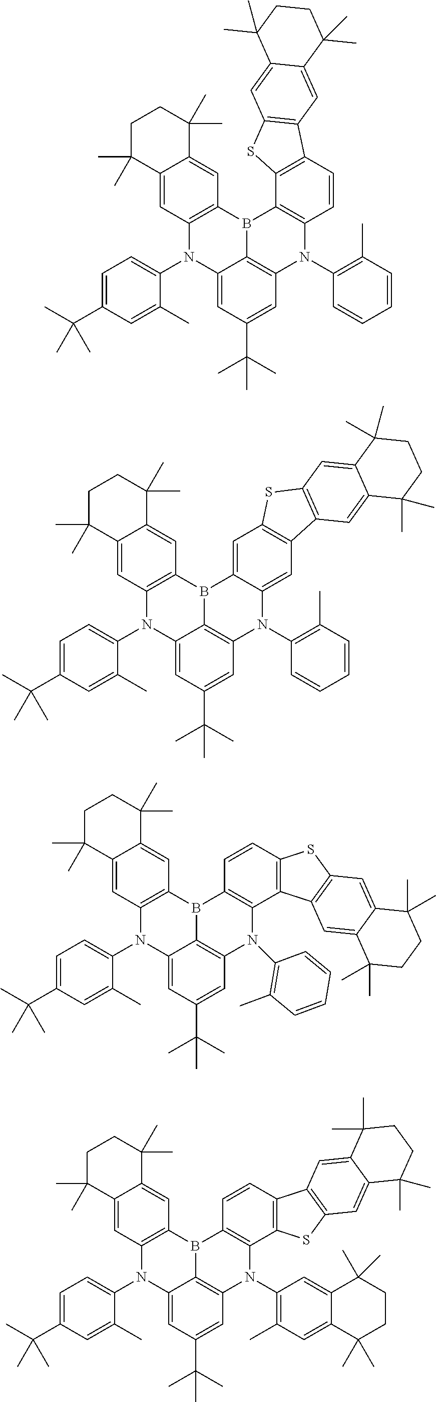

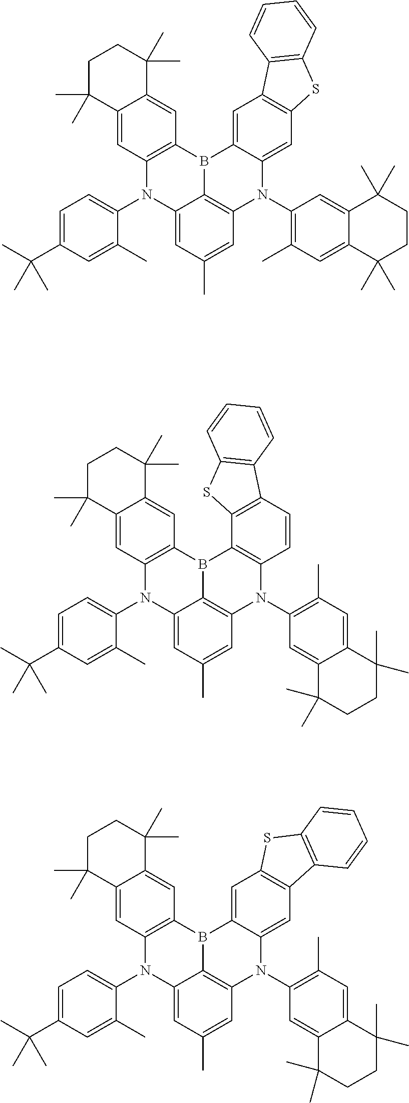

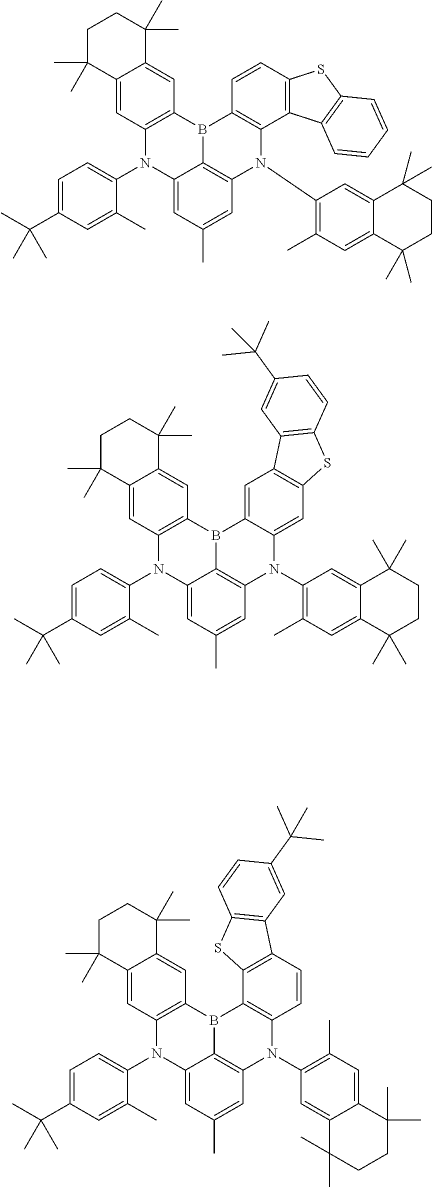

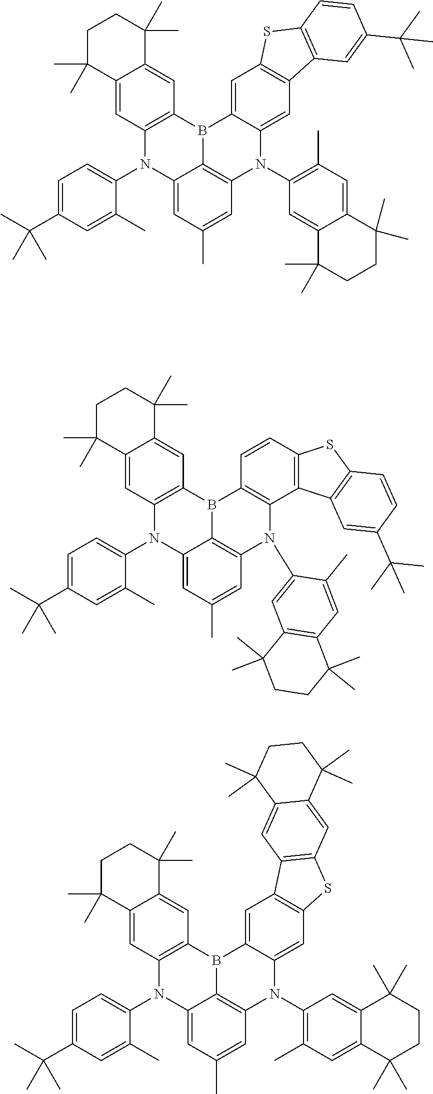

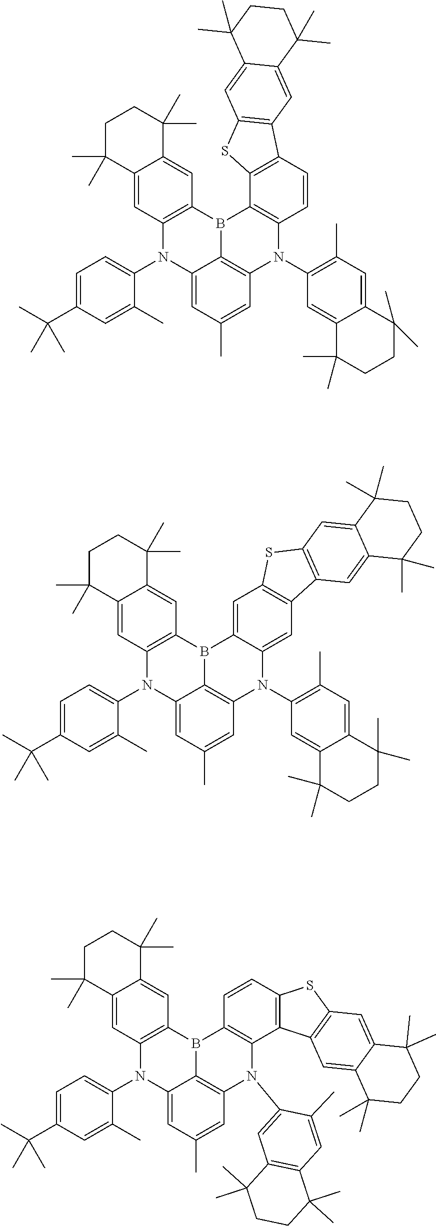

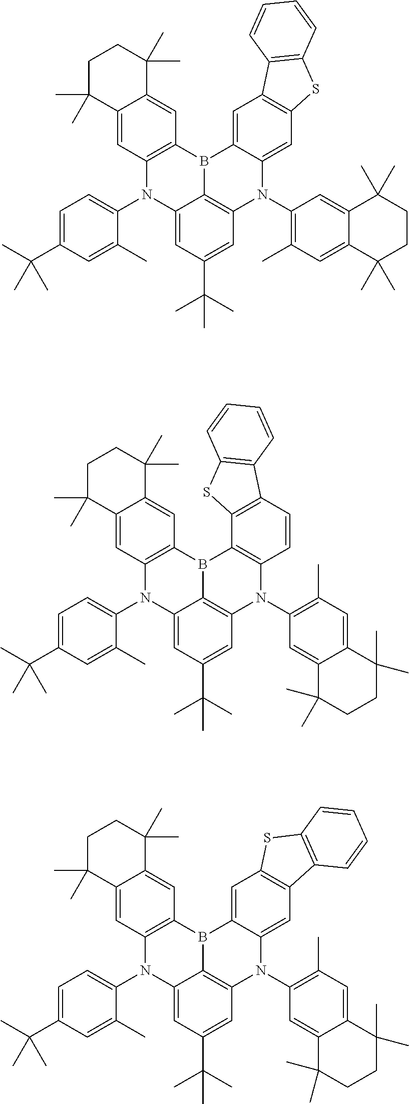

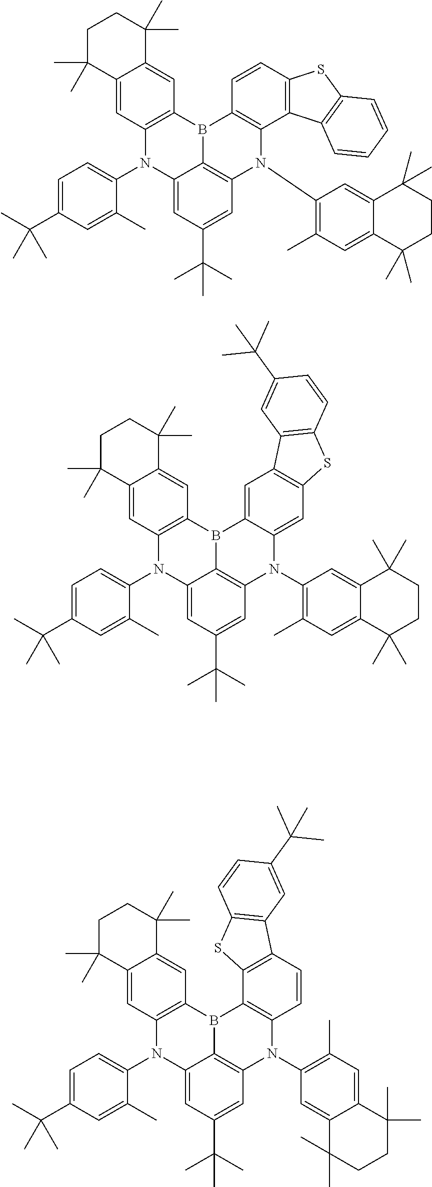

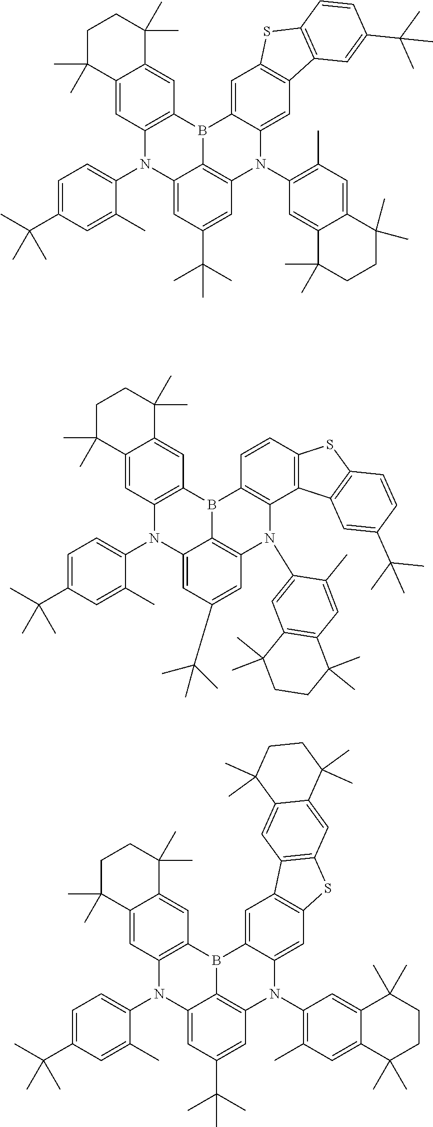

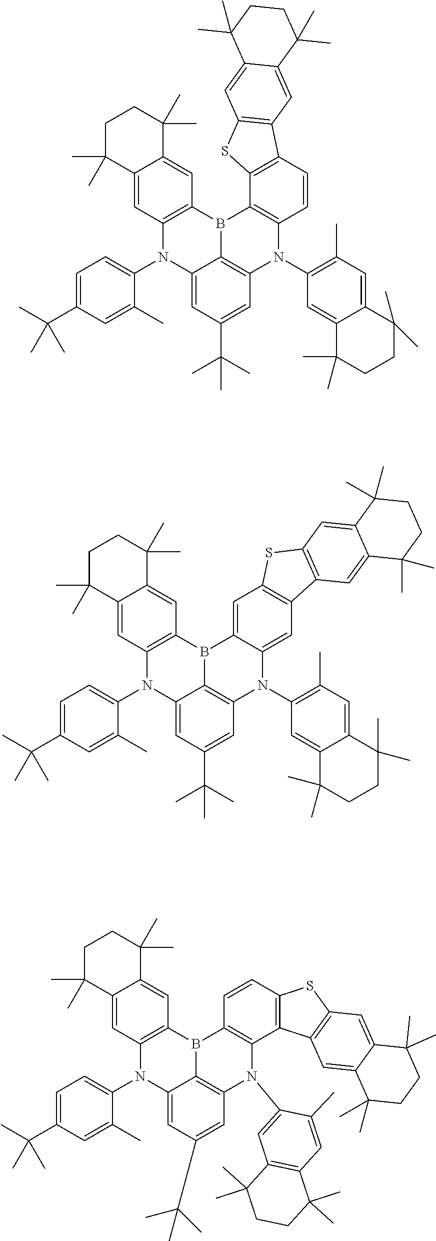

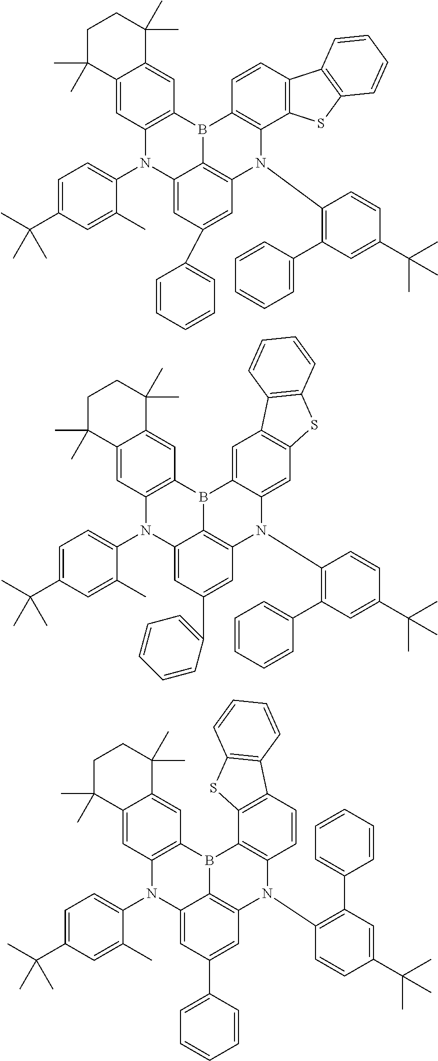

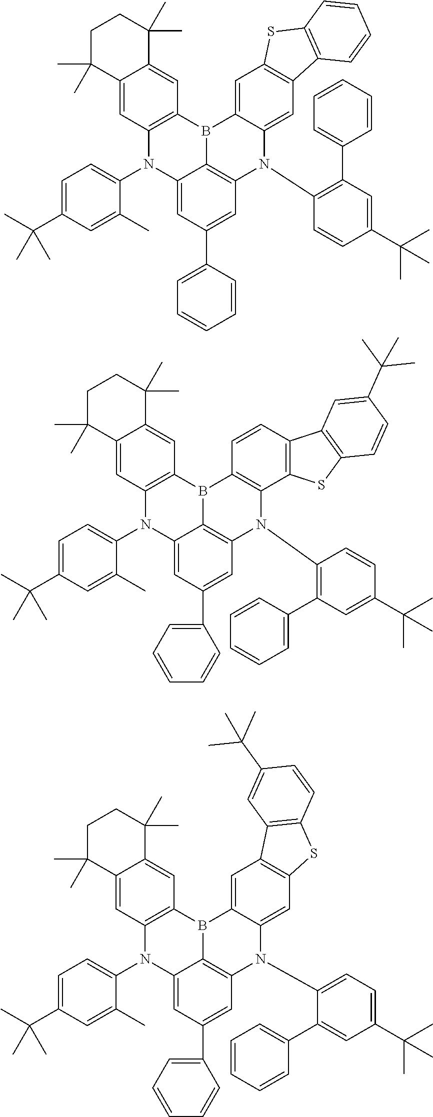

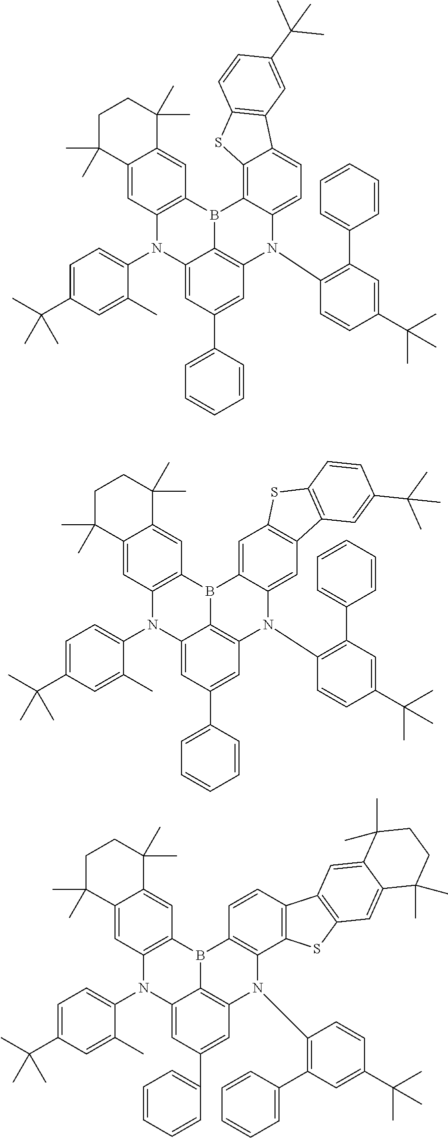

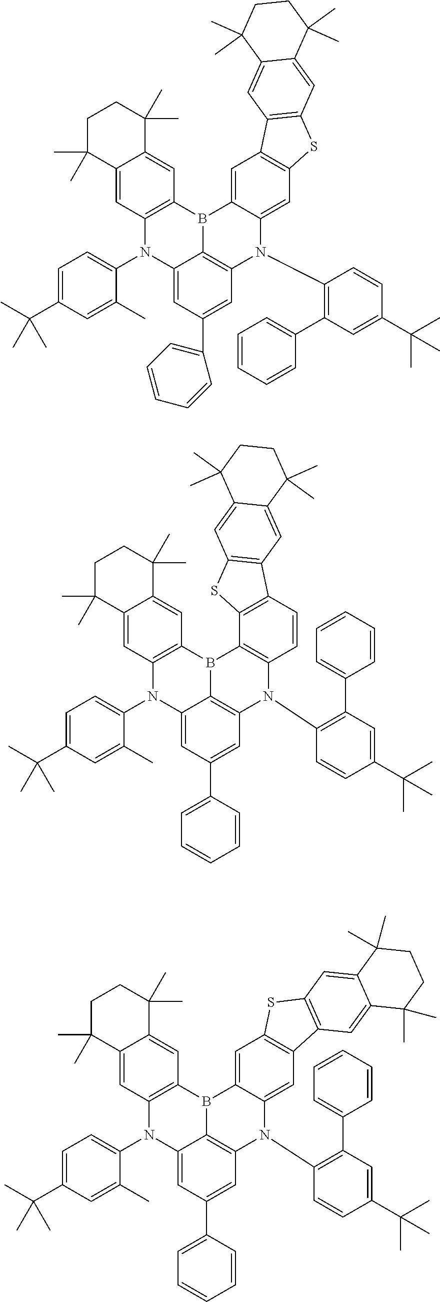

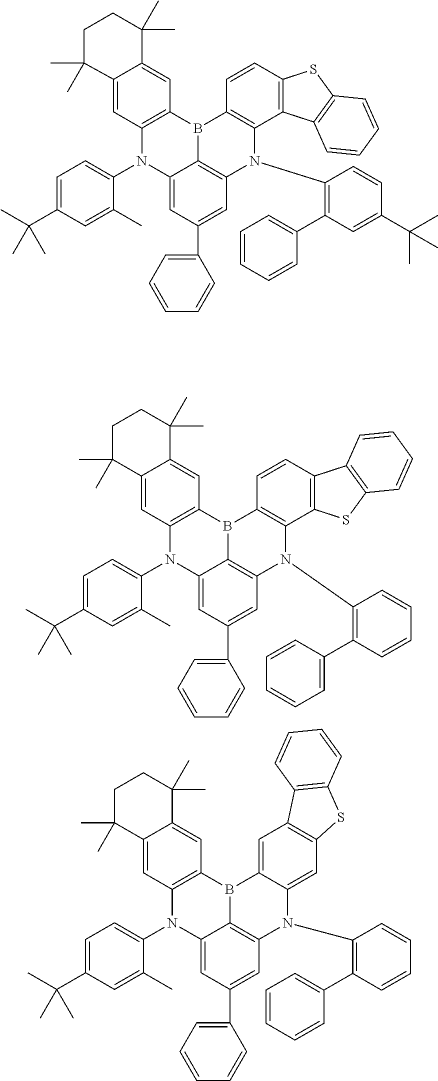

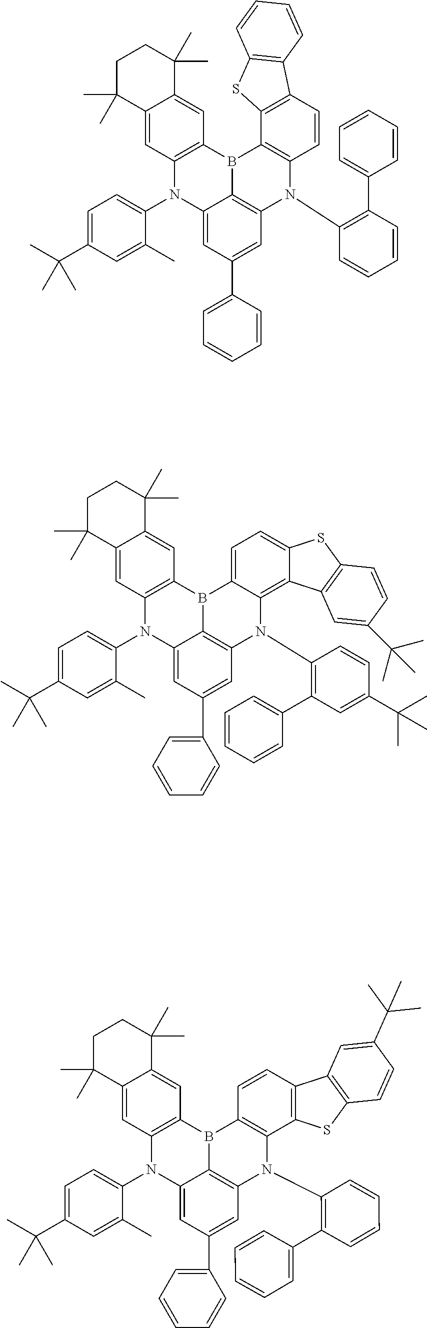

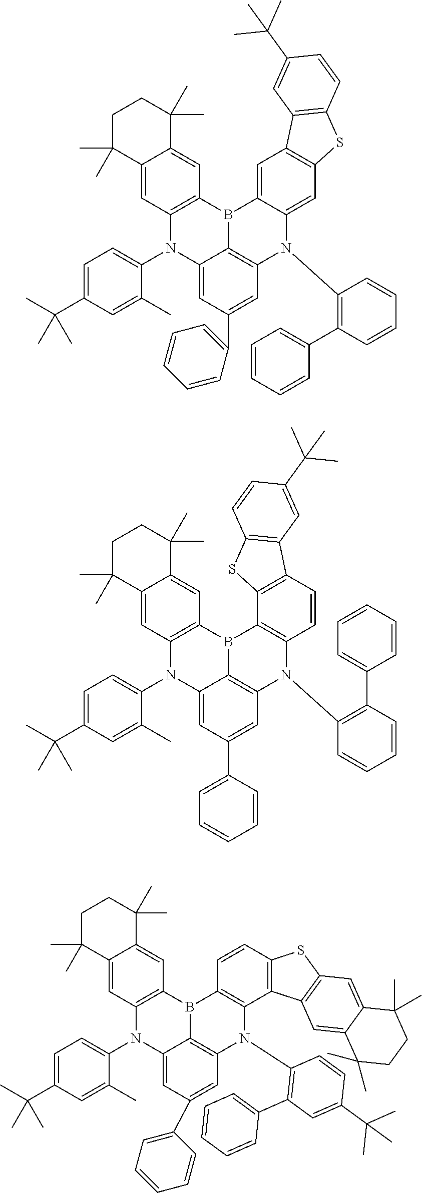

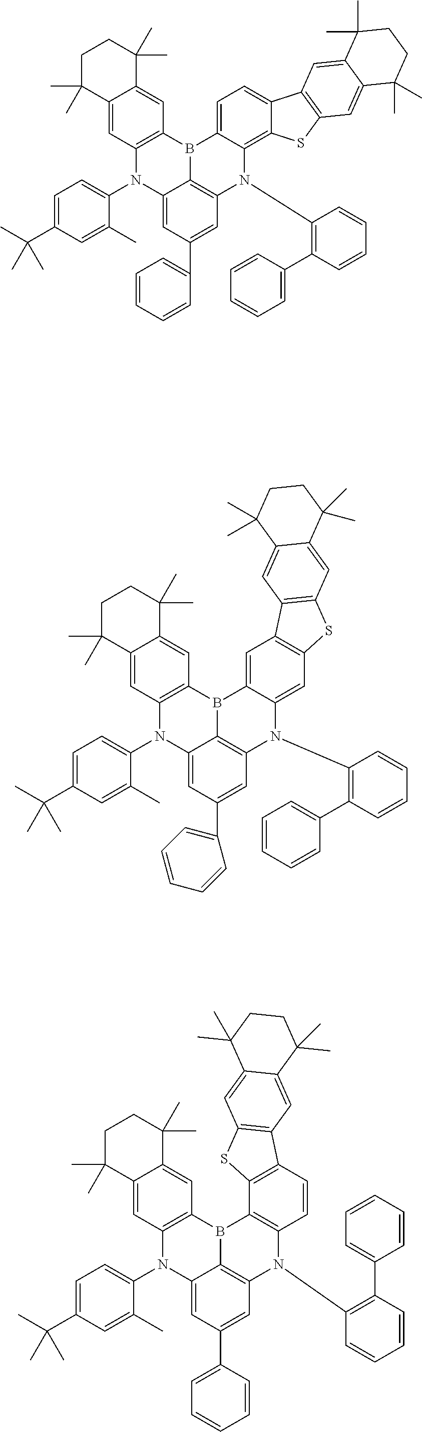

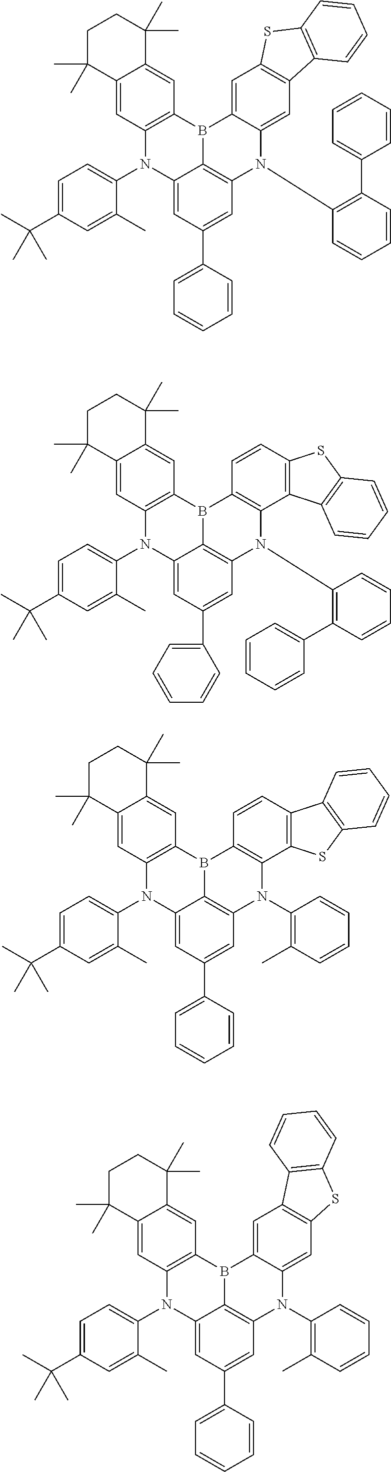

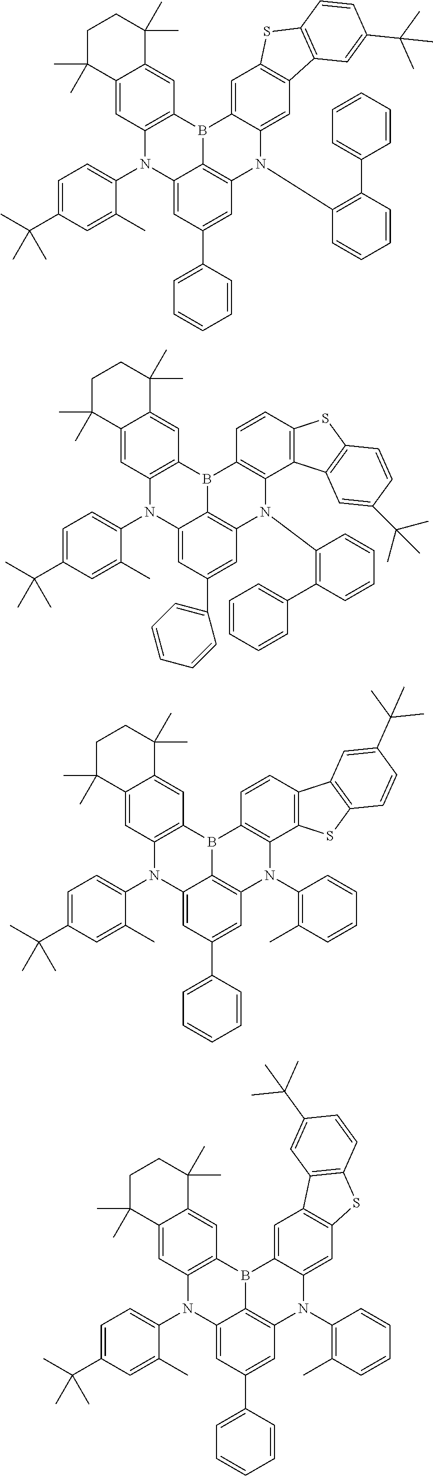

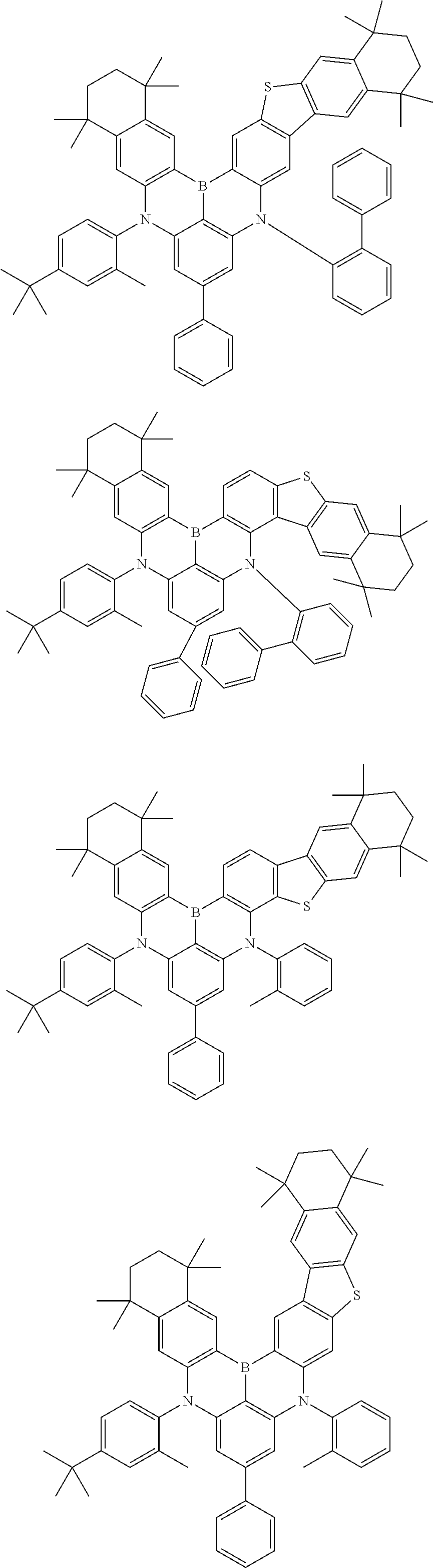

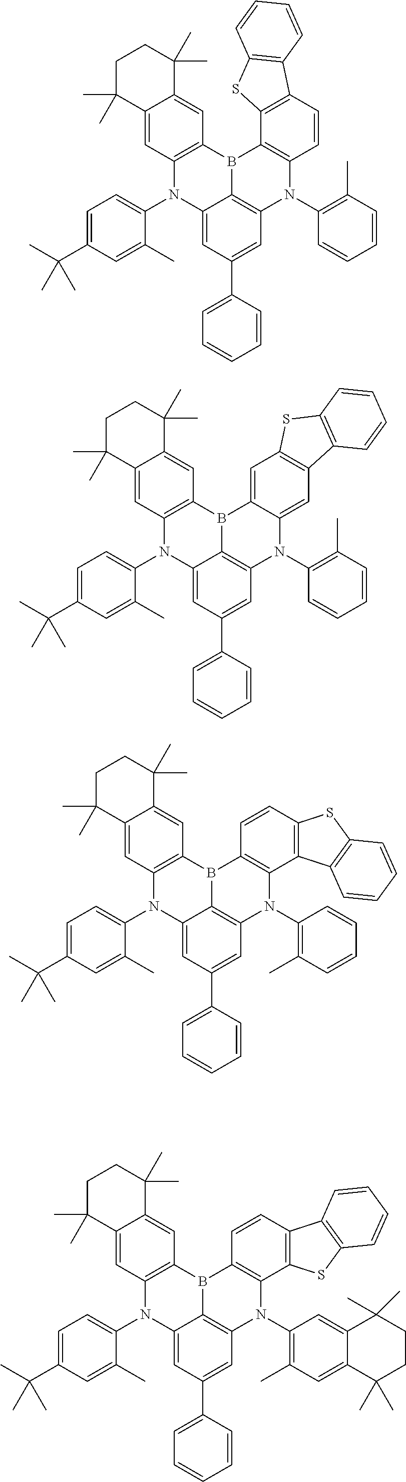 [SMILES: Cc1cc(C(C)(C)C)ccc1N1c2cc3c(cc2B2c4c1cc(-c1ccccc1)cc4N(c1ccccc1C)c1ccc4c(sc5ccccc54)c12)C(C)(C)CCC3(C)C ; Cc1cc(C(C)(C)C)ccc1N1c2cc3c(cc2B2c4cc5sc6ccccc6c5cc4N(c4ccccc4C)c4cc(-c5ccccc5)cc1c42)C(C)(C)CCC3(C)C ; Cc1cc(C(C)(C)C)ccc1N1c2cc3c(cc2B2c4ccc5sc6ccccc6c5c4N(c4ccccc4C)c4cc(-c5ccccc5)cc1c42)C(C)(C)CCC3(C)C ; Cc1cc(C(C)(C)C)ccc1N1c2cc3c(cc2B2c4ccc5c(sc6ccccc65)c4N(c4cc5c(cc4C)C(C)(C)CCC5(C)C)c4cc(-c5ccccc5)cc1c42)C(C)(C)CCC3(C)C]

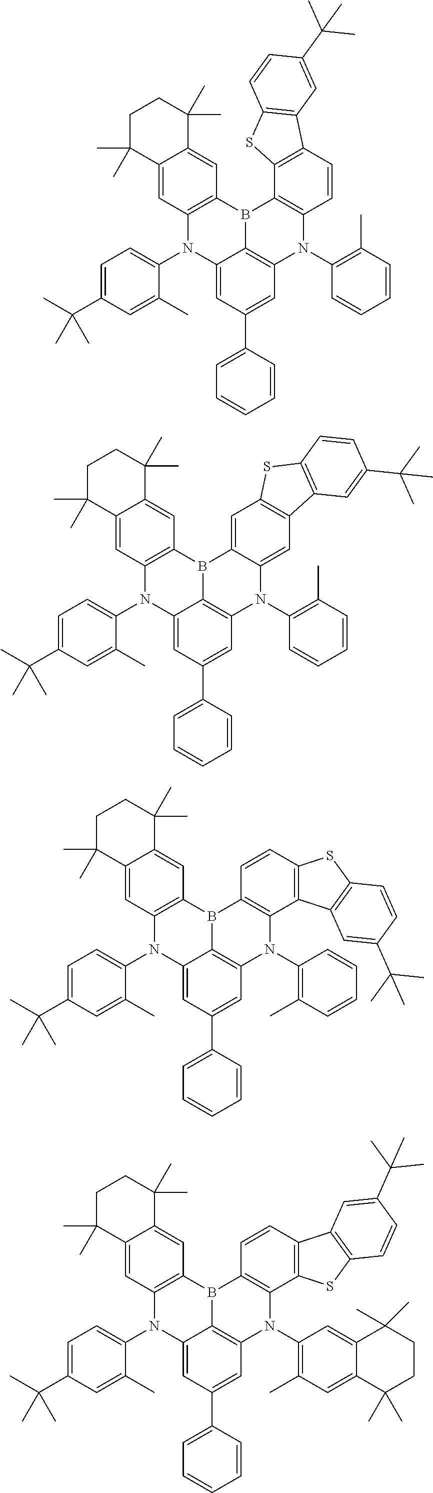

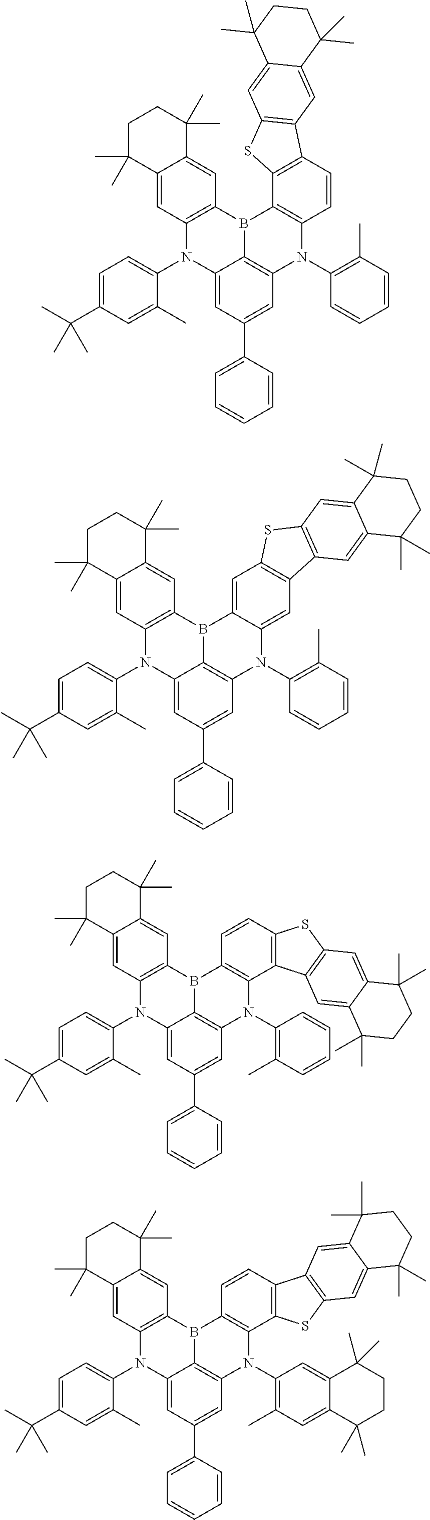

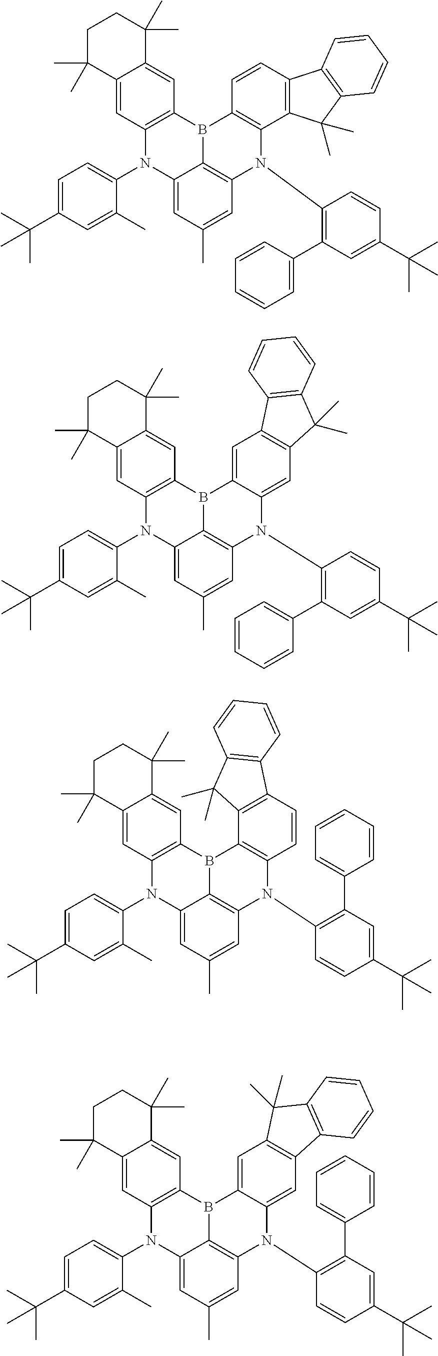

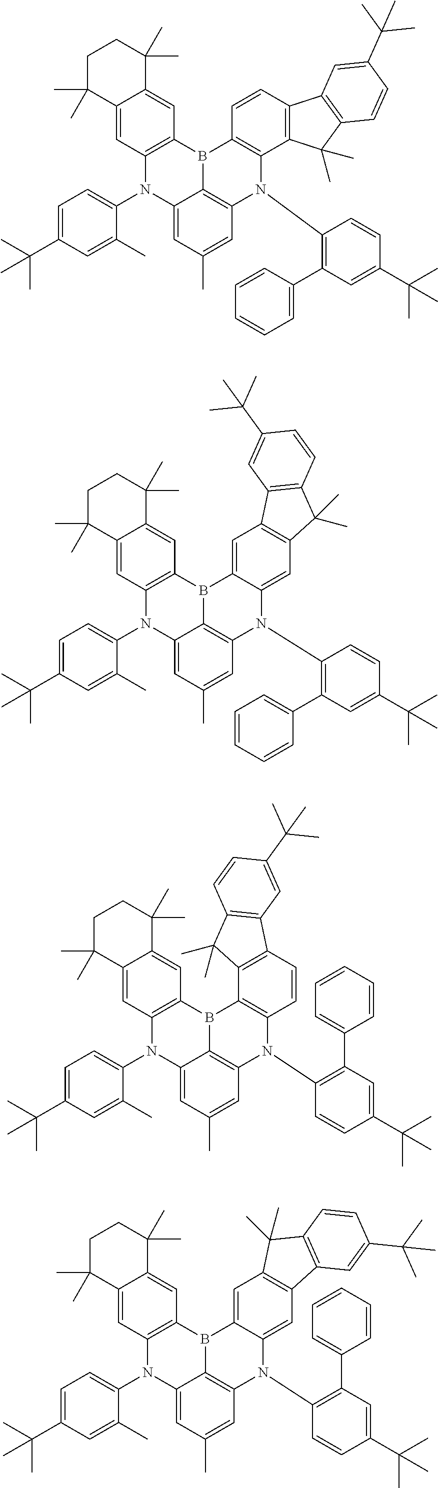

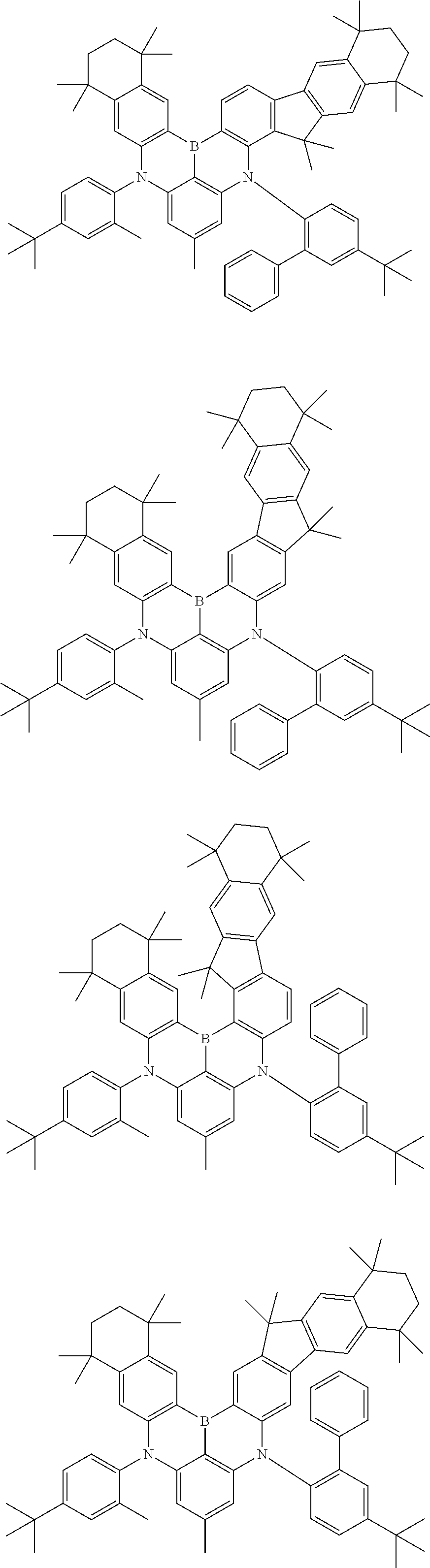

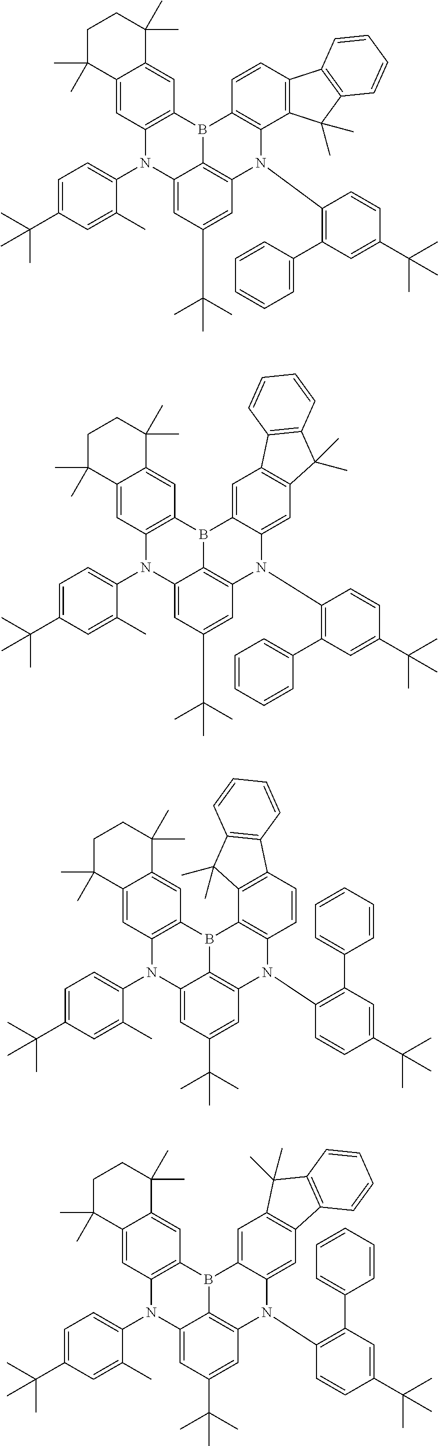

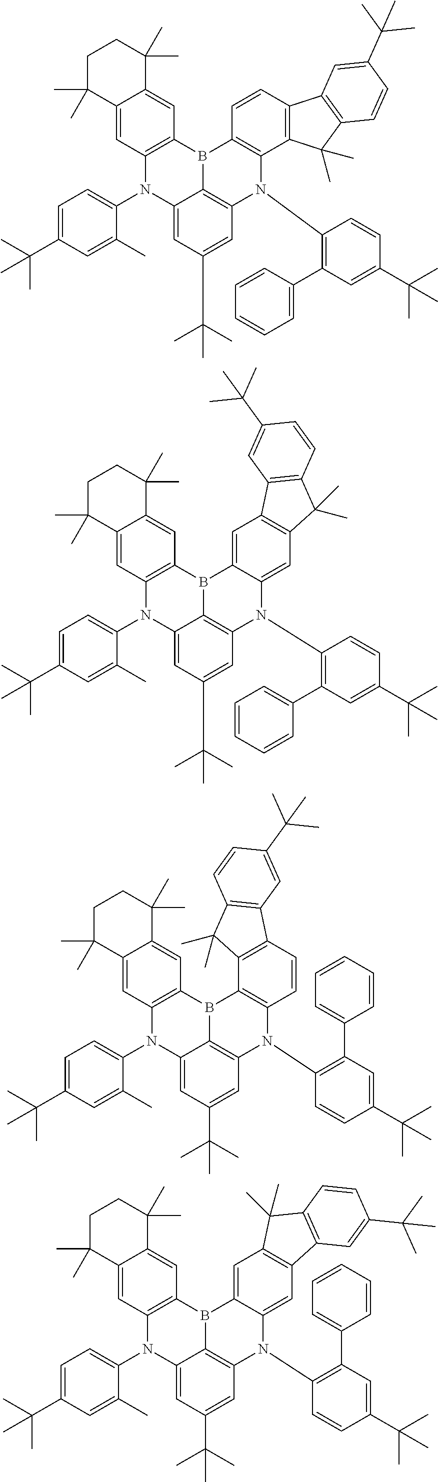

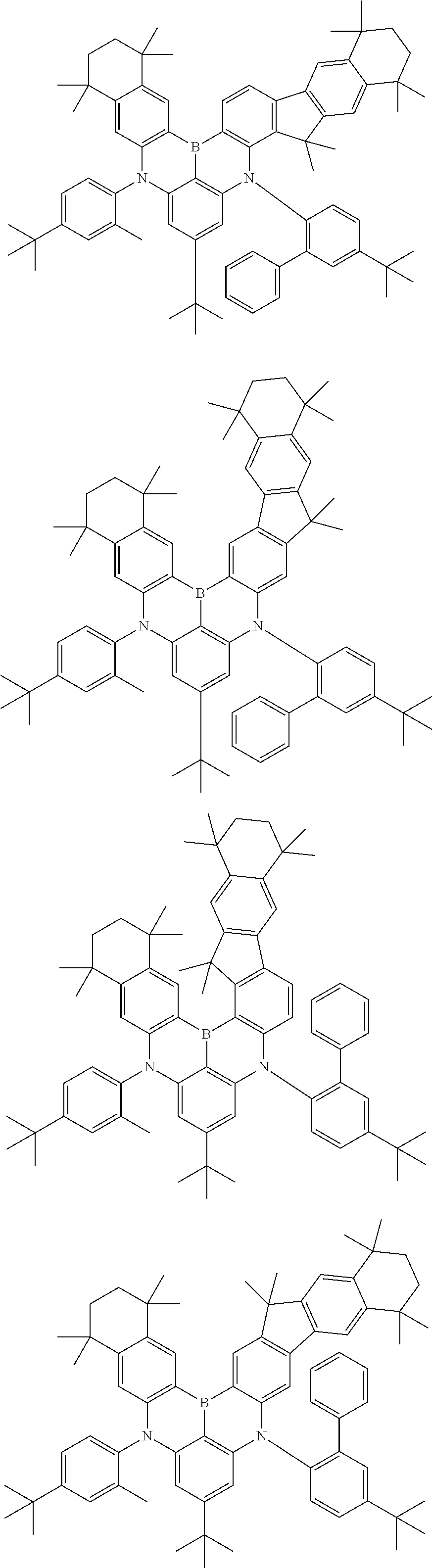

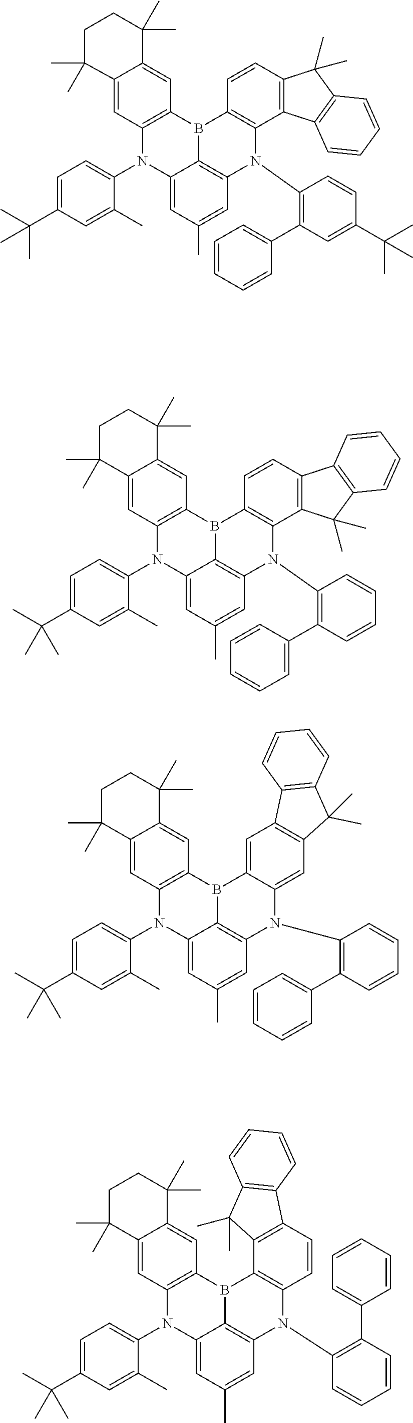

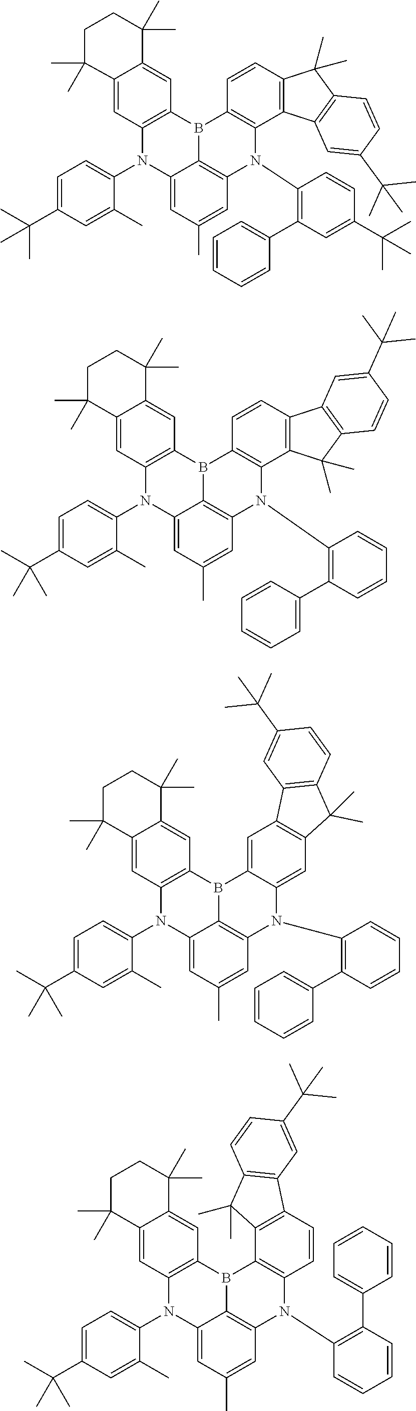

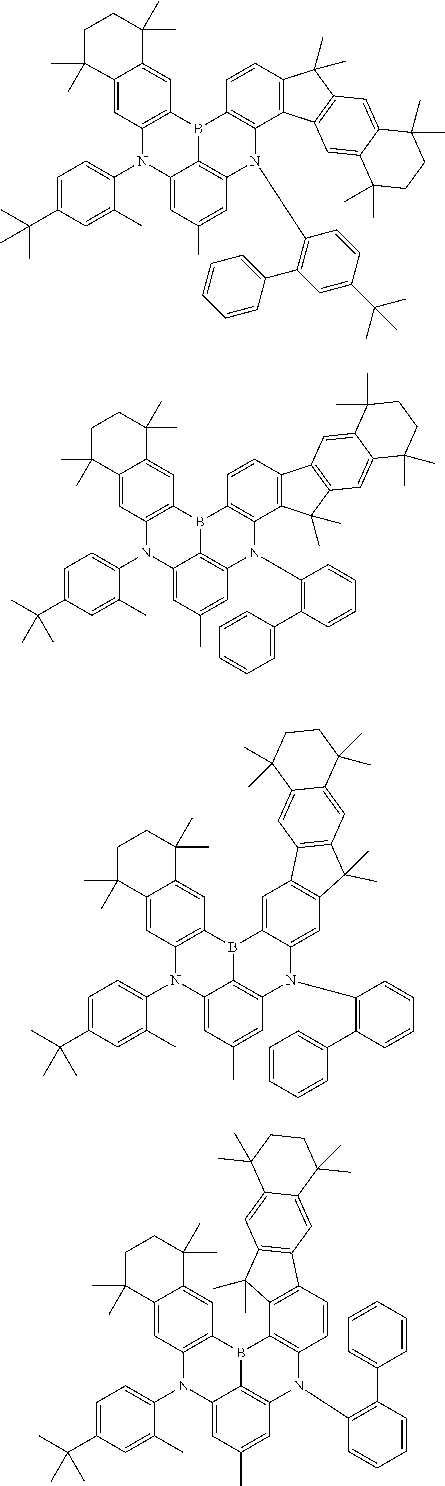

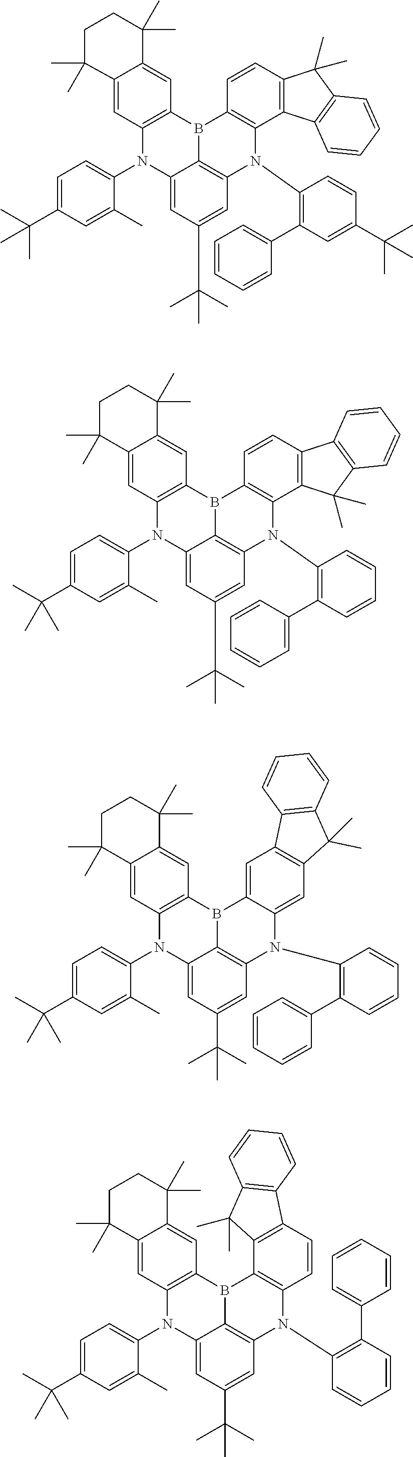

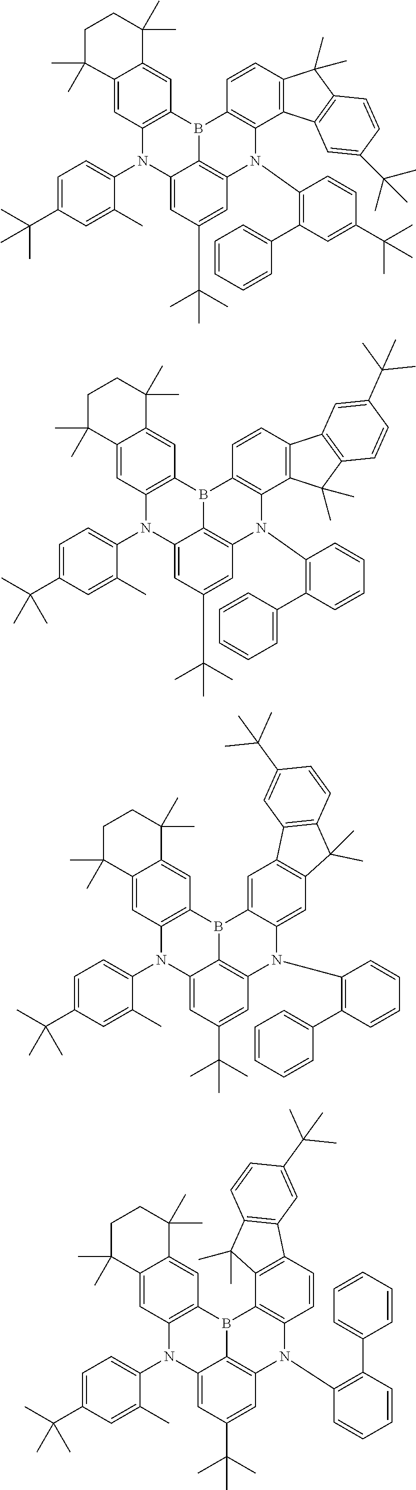

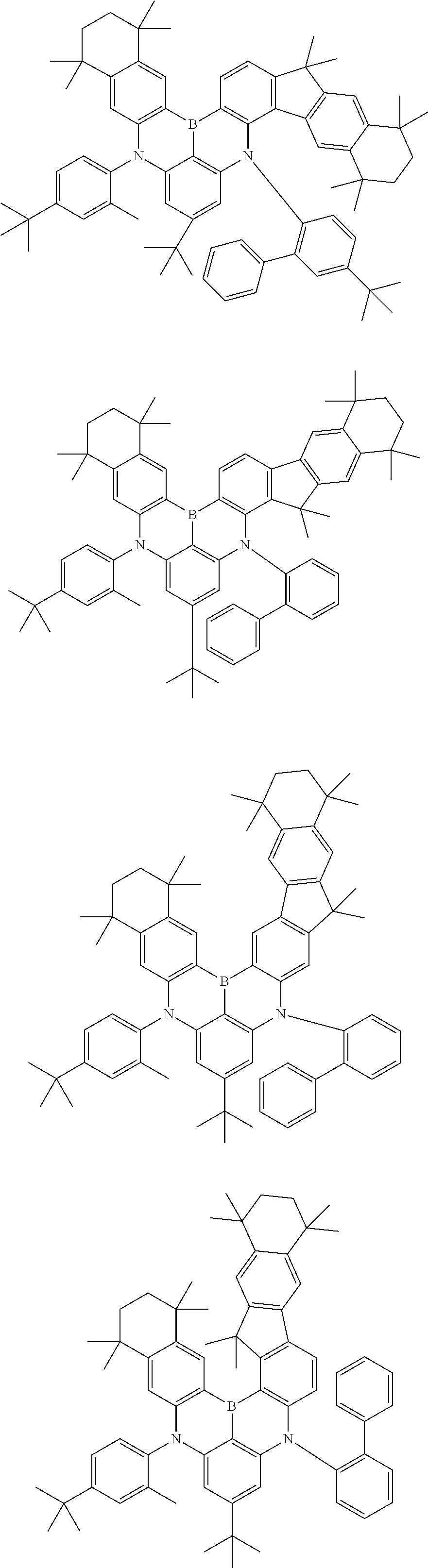

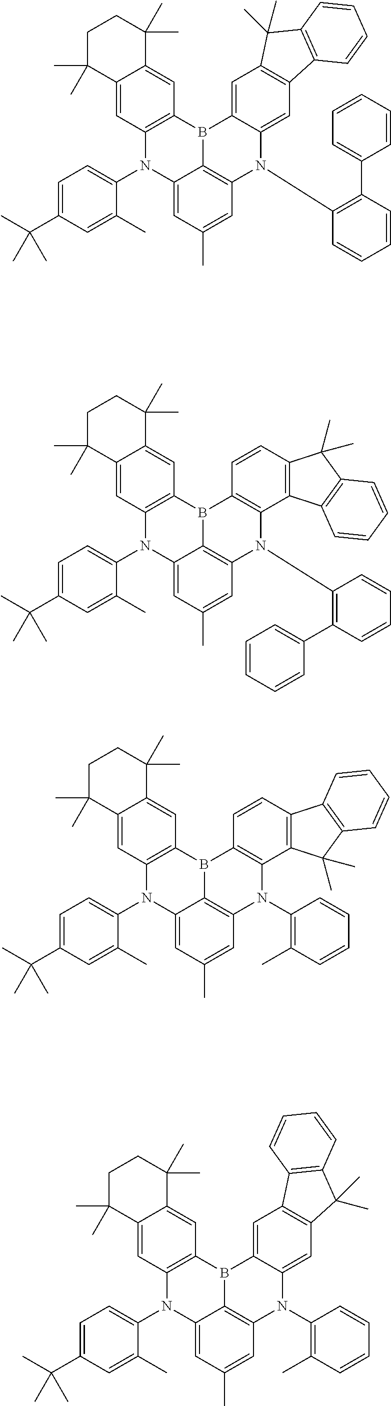 [SMILES: Cc1cc2c3c(c1)N(c1ccccc1-c1ccccc1)c1cc4c(cc1B3c1cc3c(cc1N2c1ccc(C(C)(C)C)cc1C)C(C)(C)CCC3(C)C)C(C)(C)c1ccccc1-4 ; Cc1cc2c3c(c1)N(c1ccccc1-c1ccccc1)c1c(ccc4c1-c1ccccc1C4(C)C)B3c1cc3c(cc1N2c1ccc(C(C)(C)C)cc1C)C(C)(C)CCC3(C)C ; Cc1cc2c3c(c1)N(c1ccccc1C)c1c(ccc4c1C(C)(C)c1ccccc1-4)B3c1cc3c(cc1N2c1ccc(C(C)(C)C)cc1C)C(C)(C)CCC3(C)C ; Cc1cc2c3c(c1)N(c1ccccc1C)c1cc4c(cc1B3c1cc3c(cc1N2c1ccc(C(C)(C)C)cc1C)C(C)(C)CCC3(C)C)-c1ccccc1C4(C)C]

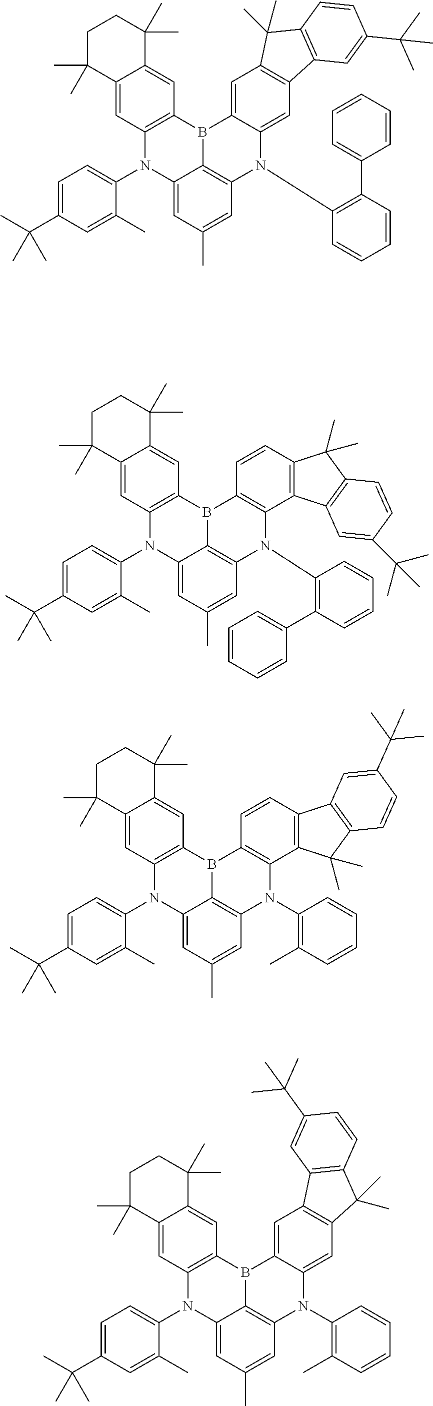

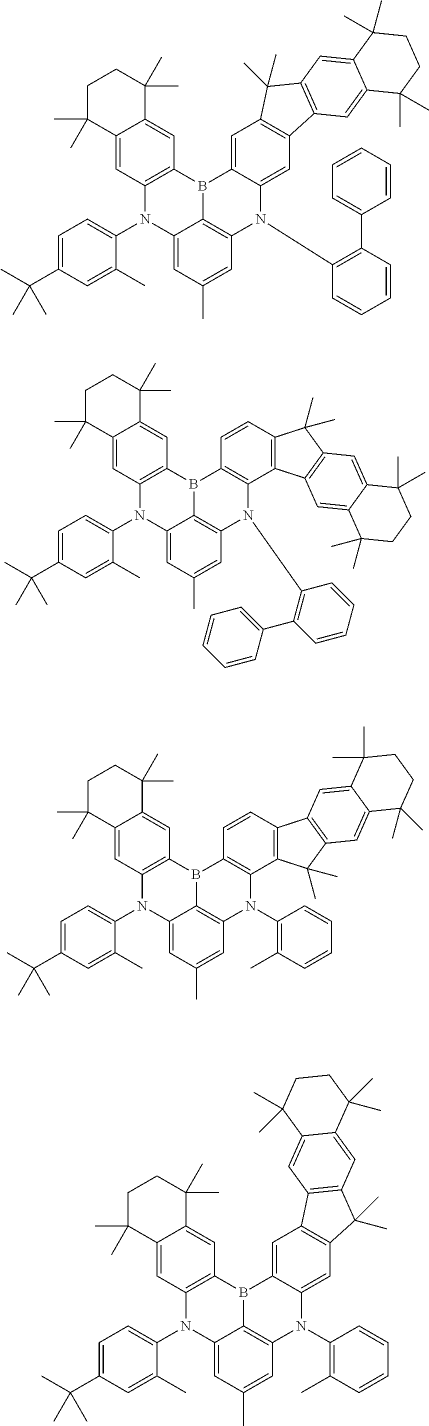

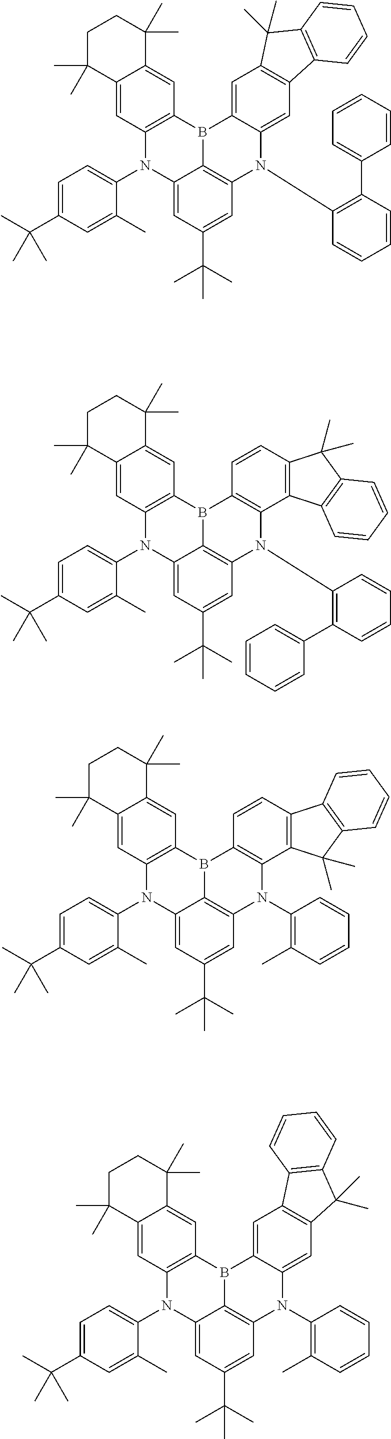 [SMILES: Cc1cc(C(C)(C)C)ccc1N1c2cc3c(cc2B2c4cc5c(cc4N(c4ccccc4-c4ccccc4)c4cc(C(C)(C)C)cc1c42)-c1ccccc1C5(C)C)C(C)(C)CCC3(C)C ; Cc1cc(C(C)(C)C)ccc1N1c2cc3c(cc2B2c4ccc5c(c4N(c4ccccc4-c4ccccc4)c4cc(C(C)(C)C)cc1c42)-c1ccccc1C5(C)C)C(C)(C)CCC3(C)C ; Cc1cc(C(C)(C)C)ccc1N1c2cc3c(cc2B2c4ccc5c(c4N(c4ccccc4C)c4cc(C(C)(C)C)cc1c42)C(C)(C)c1ccccc1-5)C(C)(C)CCC3(C)C ; Cc1cc(C(C)(C)C)ccc1N1c2cc3c(cc2B2c4cc5c(cc4N(c4ccccc4C)c4cc(C(C)(C)C)cc1c42)C(C)(C)c1ccccc1-5)C(C)(C)CCC3(C)C]

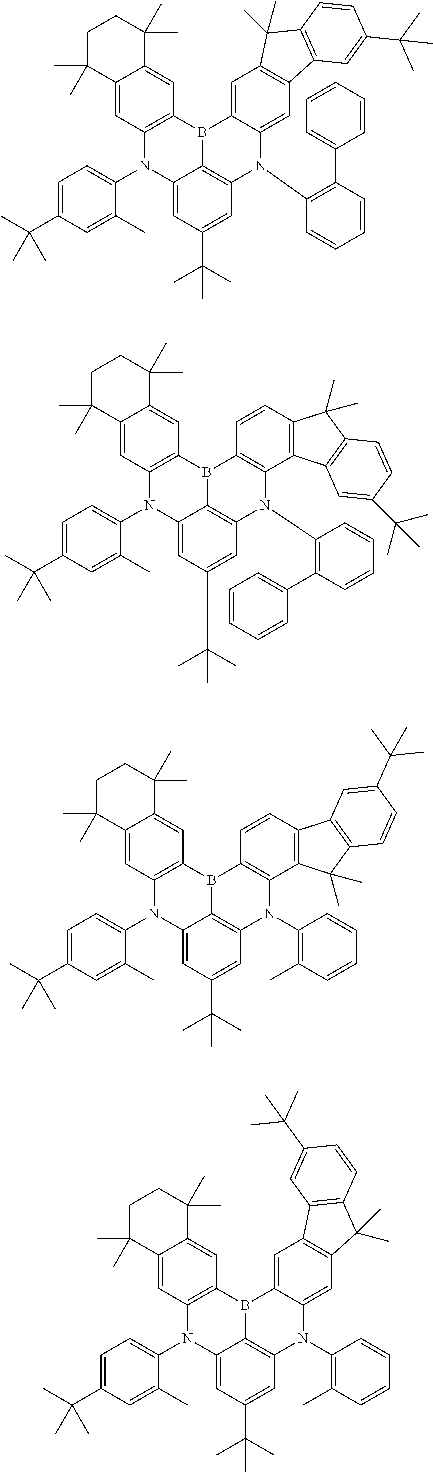

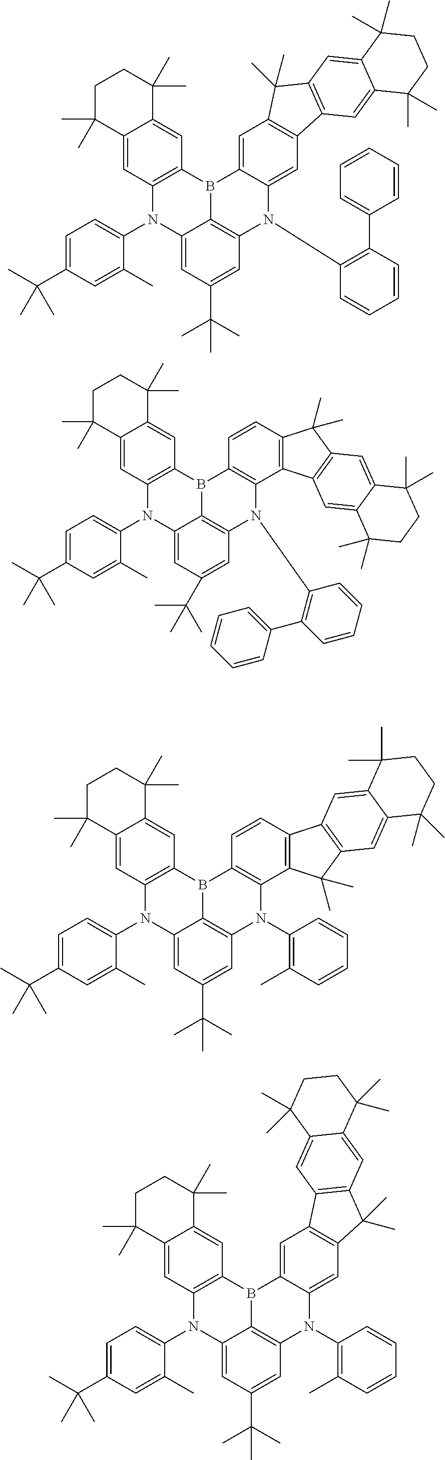

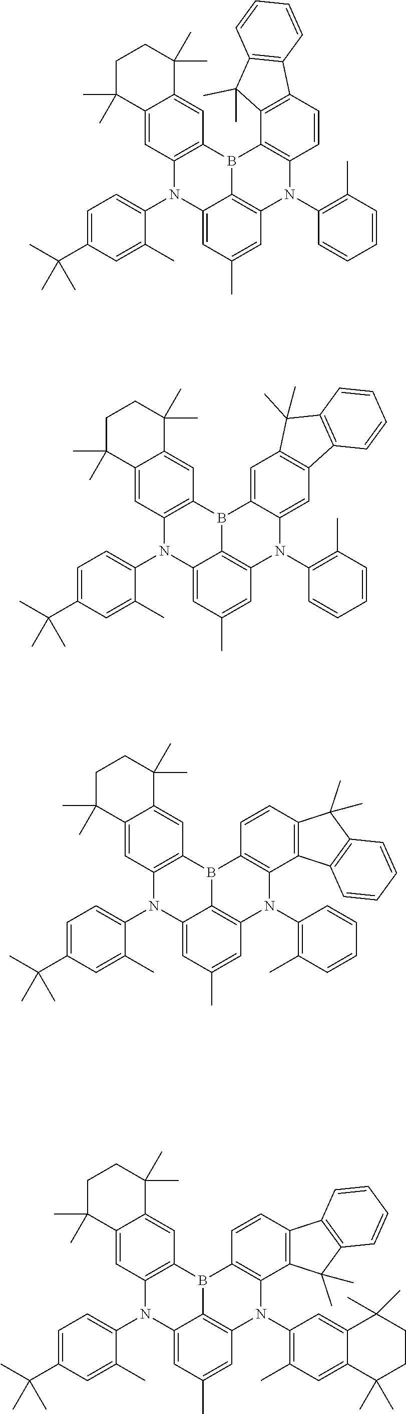 [SMILES: Cc1cc2c3c(c1)N(c1ccccc1C)c1ccc4c(c1B3c1cc3c(cc1N2c1ccc(C(C)(C)C)cc1C)C(C)(C)CCC3(C)C)C(C)(C)c1ccccc1-4 ; Cc1cc2c3c(c1)N(c1ccc(C(C)(C)C)cc1C)c1cc4c(cc1B3c1cc3c(cc1N2c1ccccc1C)-c1ccccc1C3(C)C)C(C)(C)CCC4(C)C ; Cc1cc2c3c(c1)N(c1ccccc1C)c1c(ccc4c1-c1ccccc1C4(C)C)B3c1cc3c(cc1N2c1ccc(C(C)(C)C)cc1C)C(C)(C)CCC3(C)C ; Cc1cc2c3c(c1)N(c1cc4c(cc1C)C(C)(C)CCC4(C)C)c1c(ccc4c1C(C)(C)c1ccccc1-4)B3c1cc3c(cc1N2c1ccc(C(C)(C)C)cc1C)C(C)(C)CCC3(C)C]

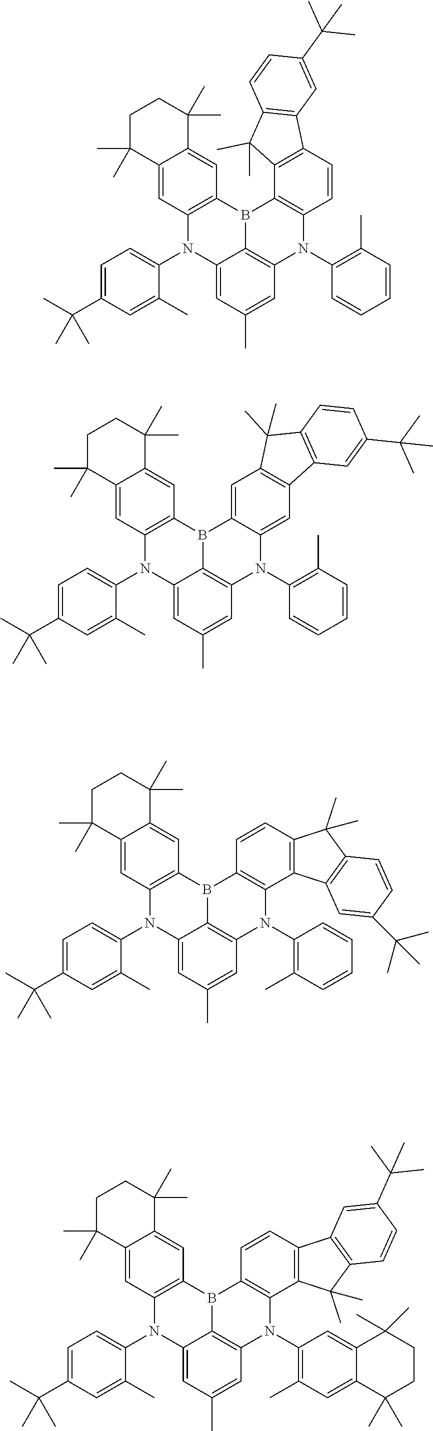

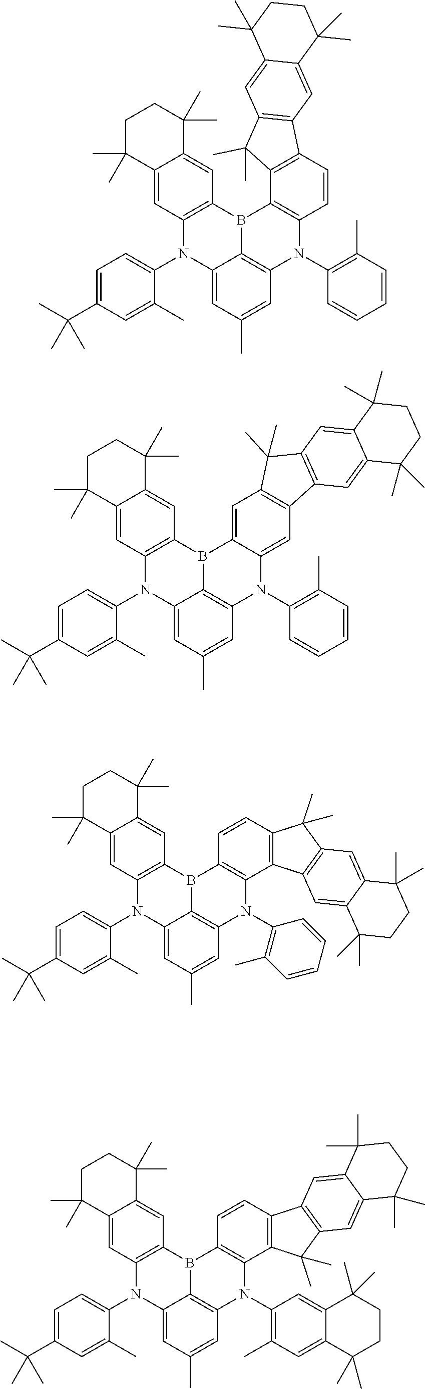

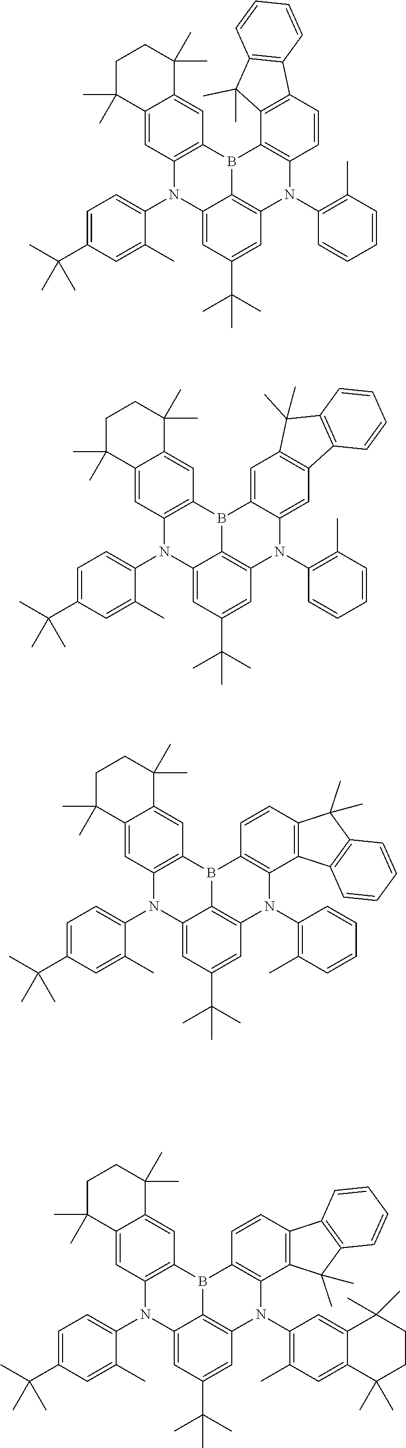 [SMILES: Cc1cc(C(C)(C)C)ccc1N1c2cc3c(cc2B2c4c1cc(C(C)(C)C)cc4N(c1ccccc1C)c1ccc4c(c12)C(C)(C)c1ccccc1-4)C(C)(C)CCC3(C)C ; Cc1ccccc1N1c2cc3c(cc2B2c4cc5c(cc4N(c4ccc(C(C)(C)C)cc4C)c4cc(C(C)(C)C)cc1c42)C(C)(C)CCC5(C)C)C(C)(C)c1ccccc1-3 ; Cc1cc(C(C)(C)C)ccc1N1c2cc3c(cc2B2c4ccc5c(c4N(c4ccccc4C)c4cc(C(C)(C)C)cc1c42)-c1ccccc1C5(C)C)C(C)(C)CCC3(C)C ; Cc1cc(C(C)(C)C)ccc1N1c2cc3c(cc2B2c4ccc5c(c4N(c4cc6c(cc4C)C(C)(C)CCC6(C)C)c4cc(C(C)(C)C)cc1c42)C(C)(C)c1ccccc1-5)C(C)(C)CCC3(C)C]

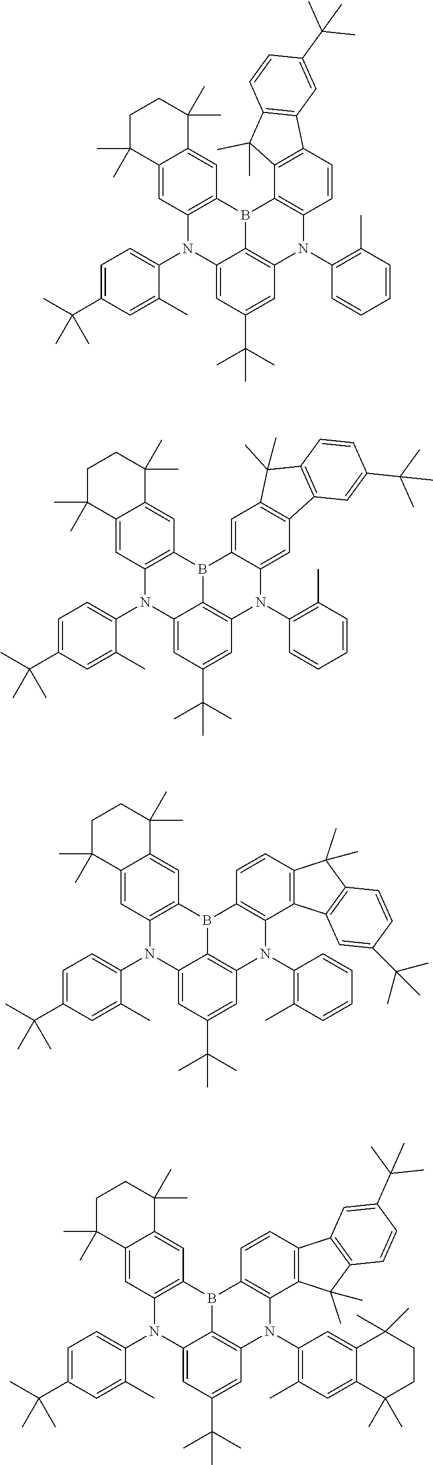

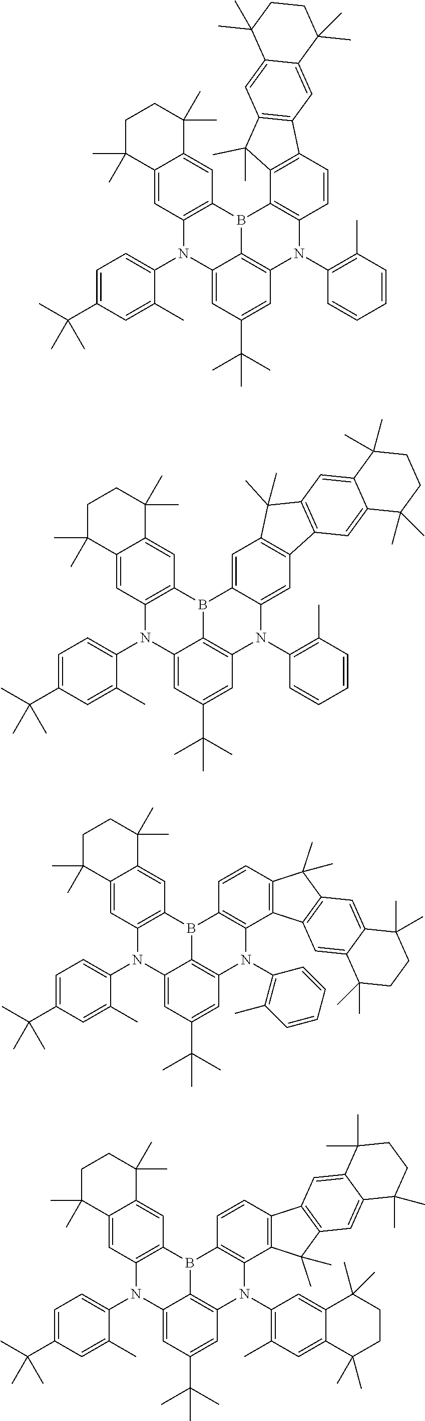

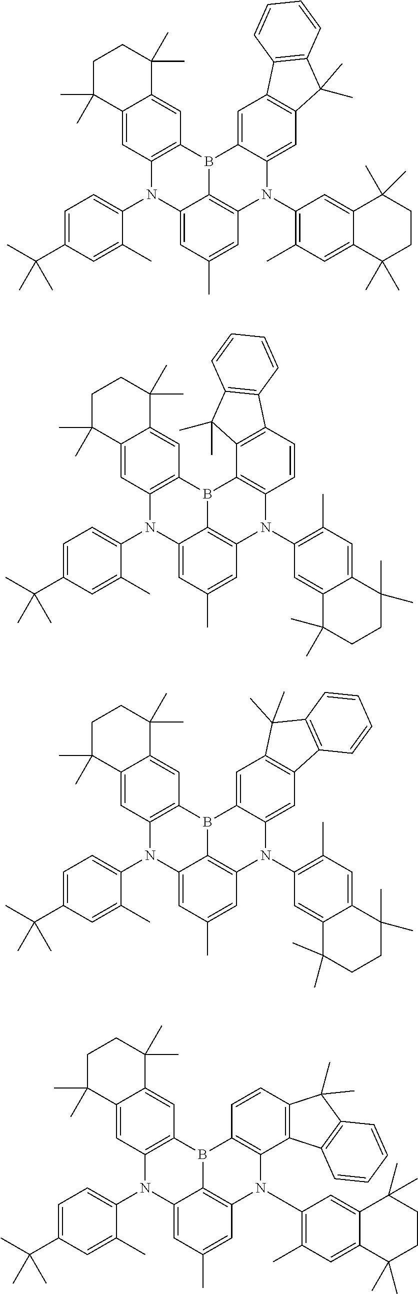

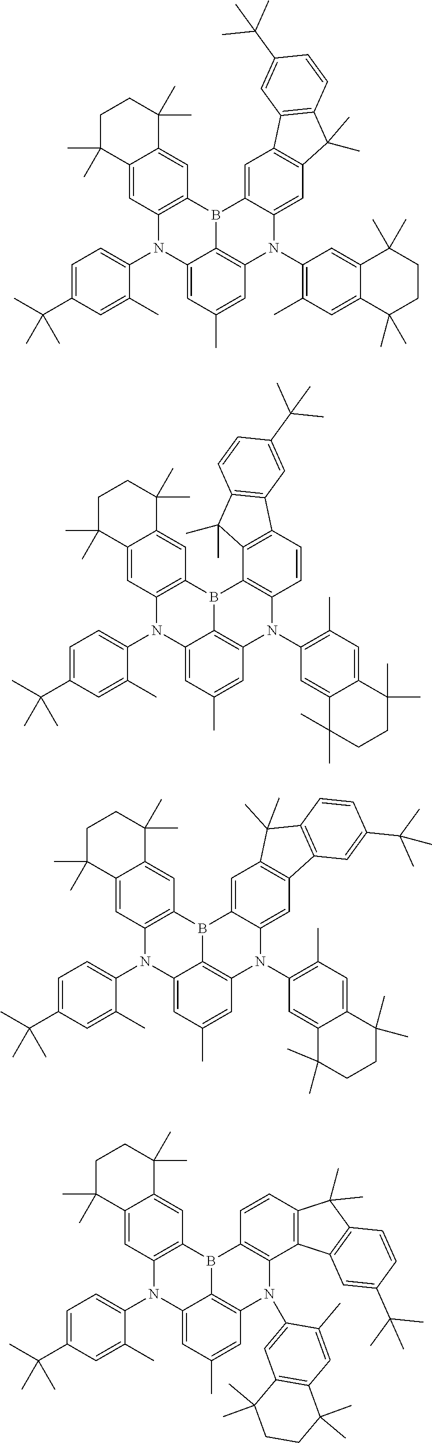

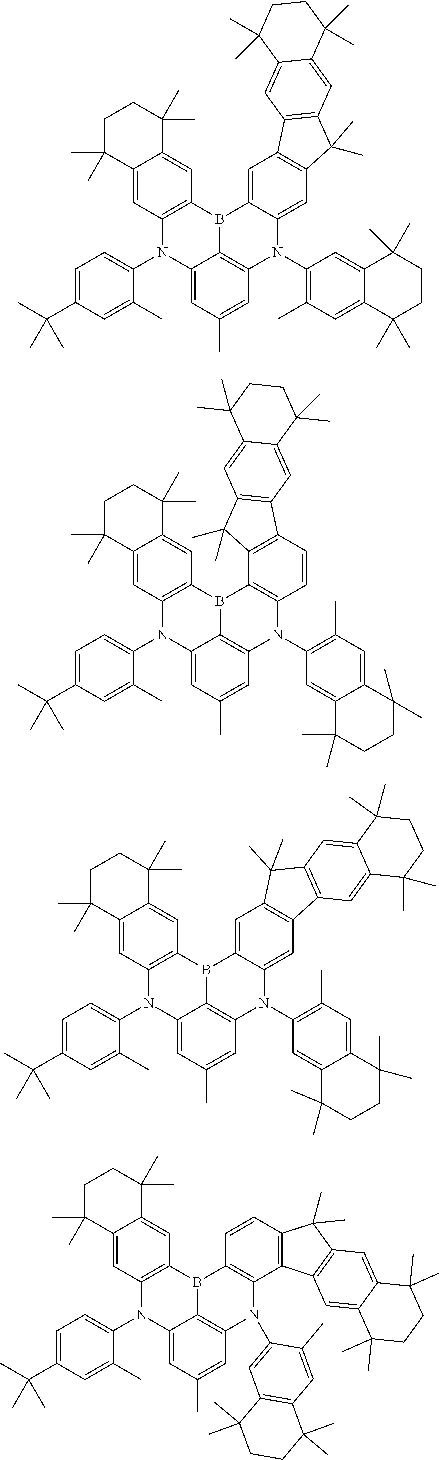

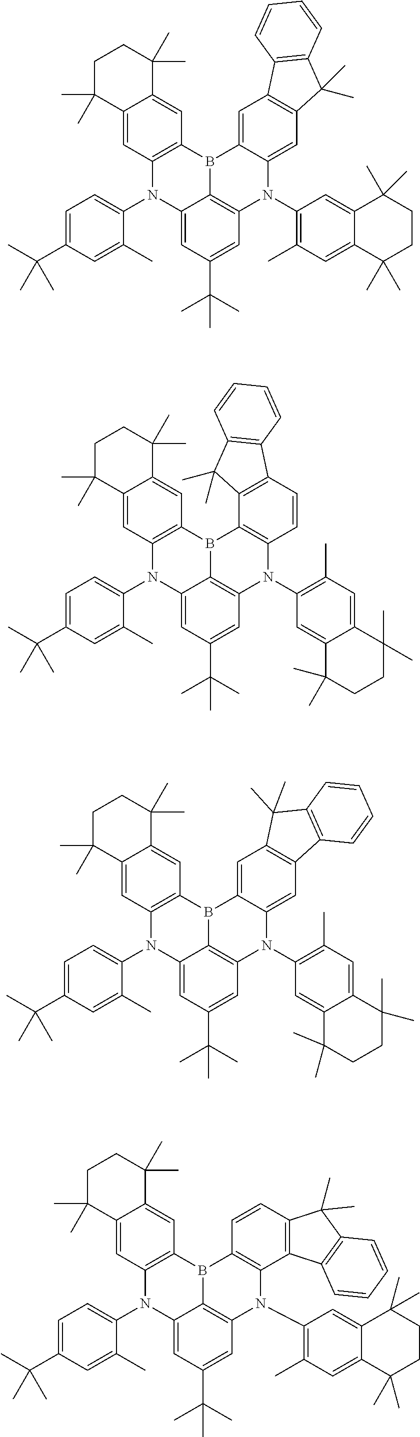

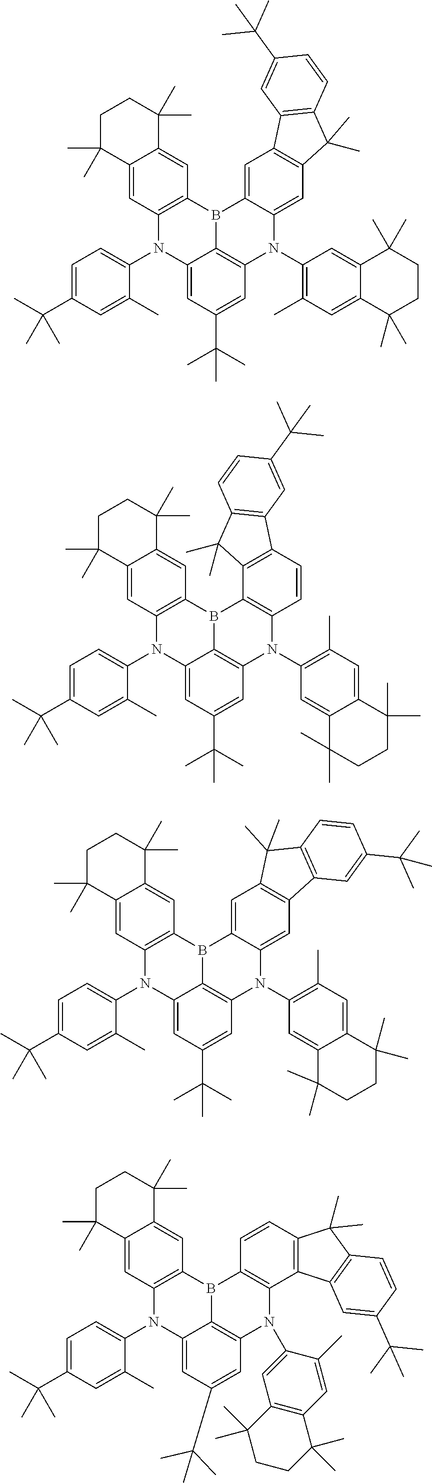

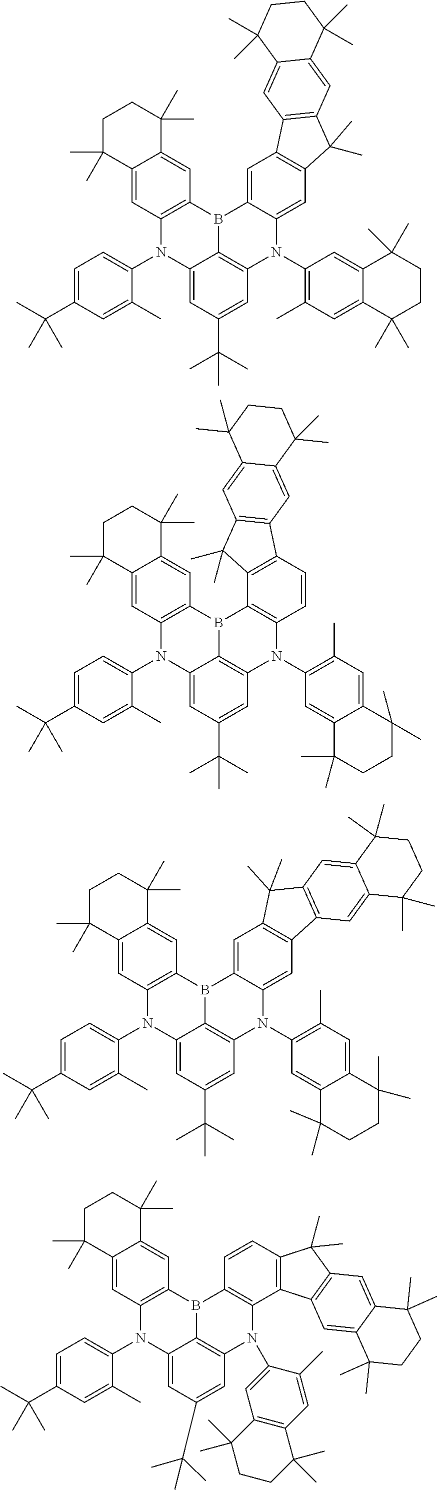

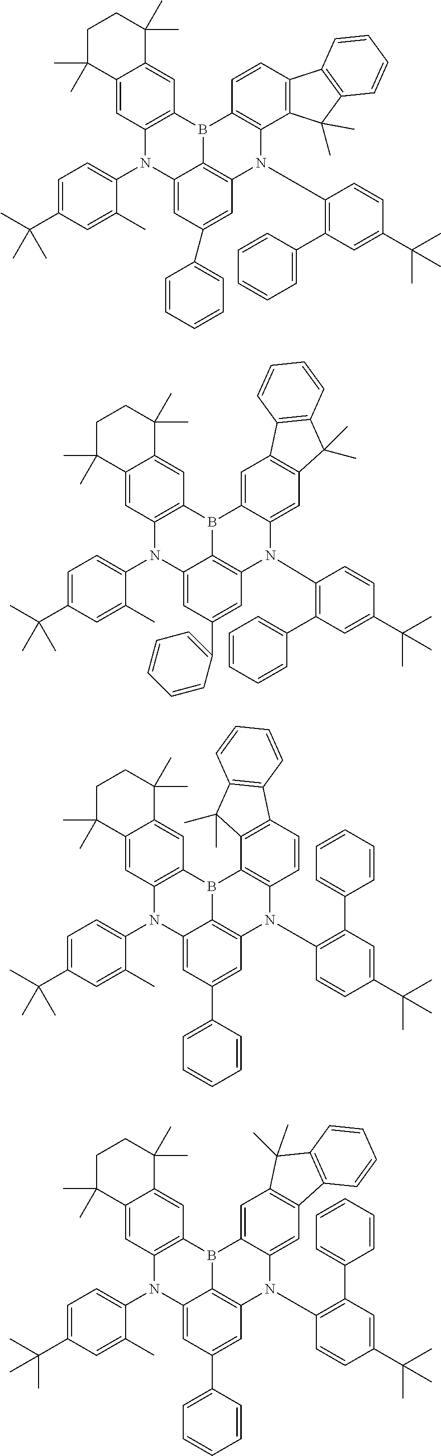

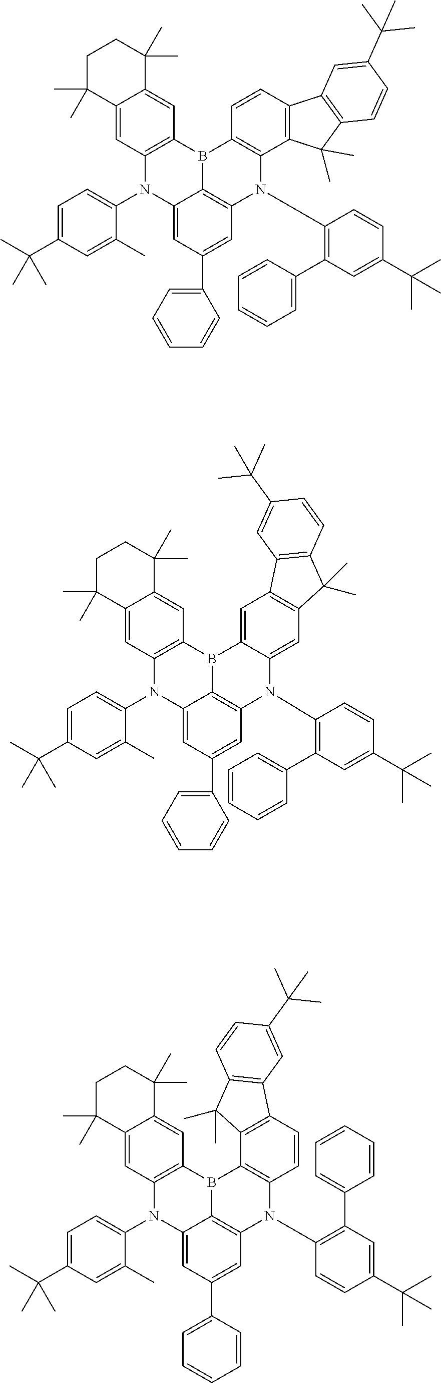

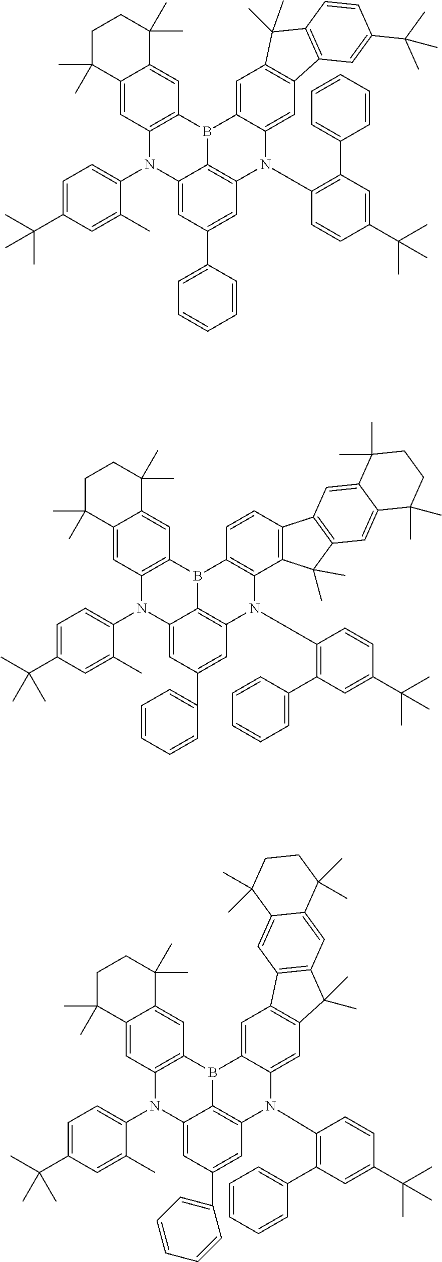

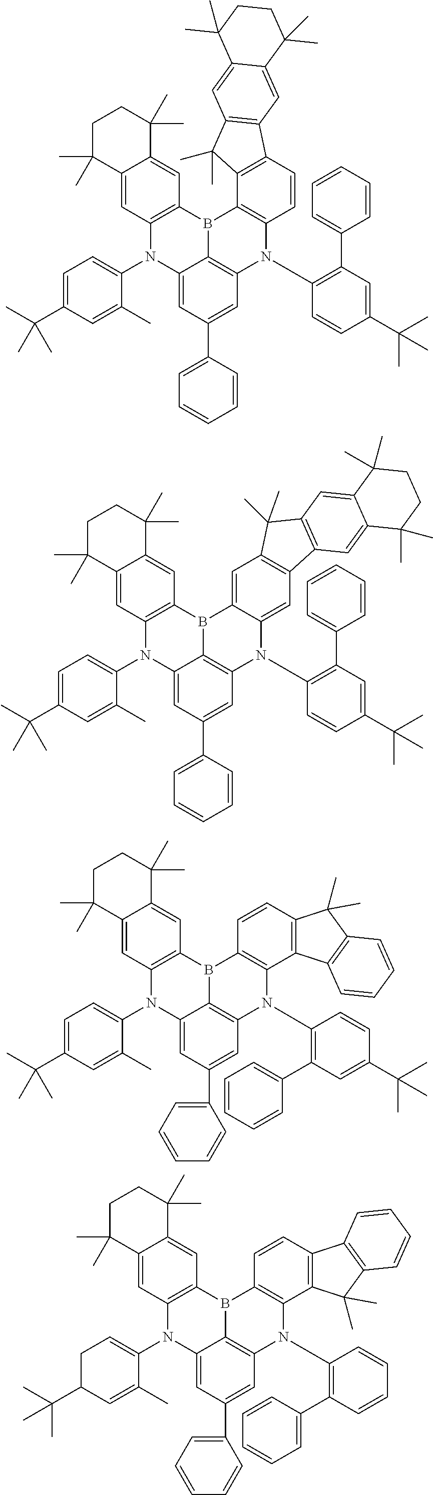

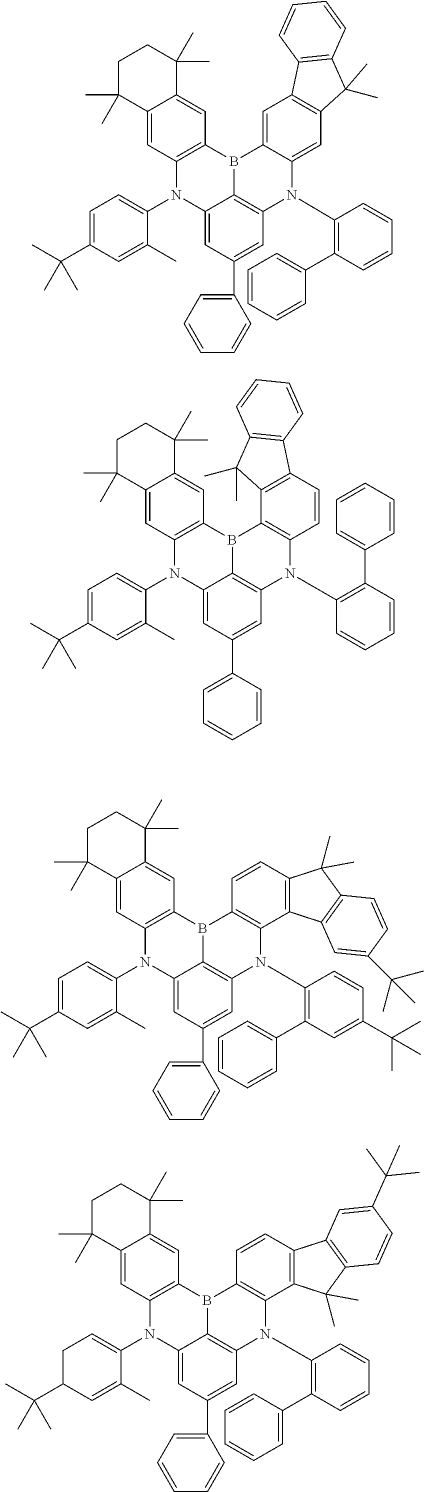

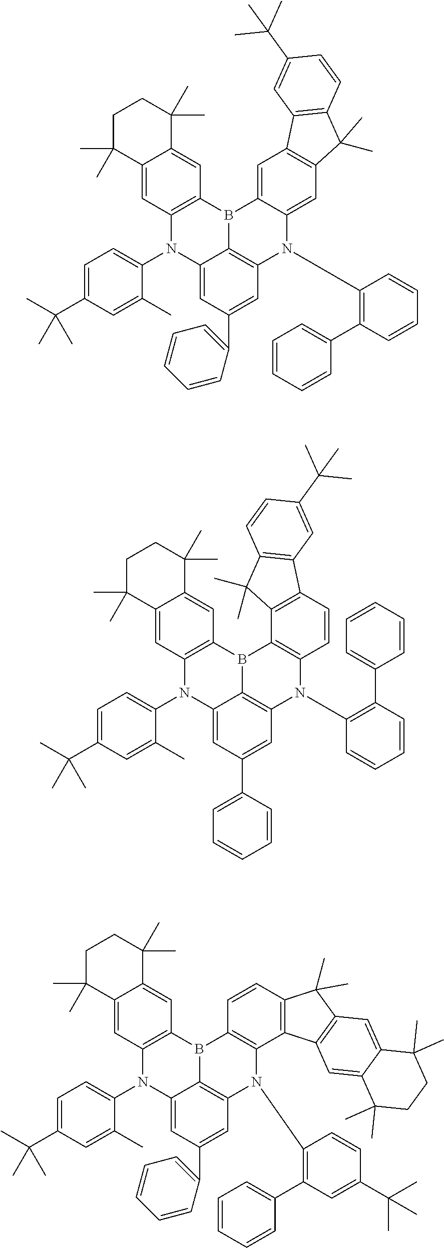 [SMILES: Cc1cc(C(C)(C)C)ccc1N1c2cc3c(cc2B2c4cc5c(cc4N(c4ccccc4-c4ccccc4)c4cc(-c6ccccc6)cc1c42)C(C)(C)c1ccc(C(C)(C)C)cc1-5)C(C)(C)CCC3(C)C ; Cc1cc(C(C)(C)C)ccc1N1c2cc3c(cc2B2c4c1cc(-c1ccccc1)cc4N(c1ccccc1-c1ccccc1)c1ccc4c(c12)C(C)(C)c1ccc(C(C)(C)C)cc1-4)C(C)(C)CCC3(C)C ; Cc1cc(C(C)(C)C)ccc1N1c2cc3c(cc2B2c4ccc5c(c4N(c4ccc(C(C)(C)C)cc4-c4ccccc4)c4cc(-c6ccccc6)cc1c42)-c1cc2c(cc1C5(C)C)C(C)(C)CCC2(C)C)C(C)(C)CCC3(C)C]

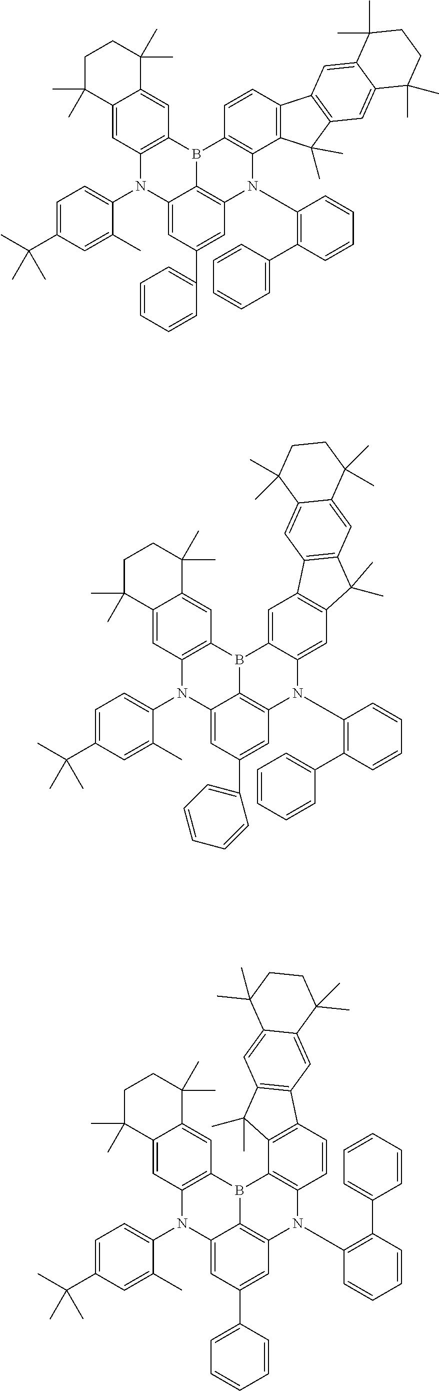

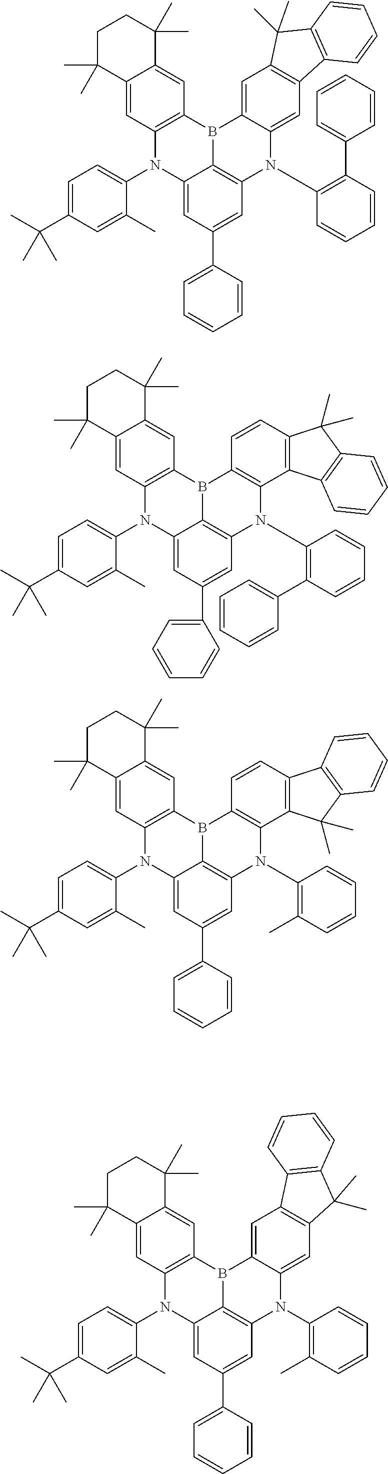

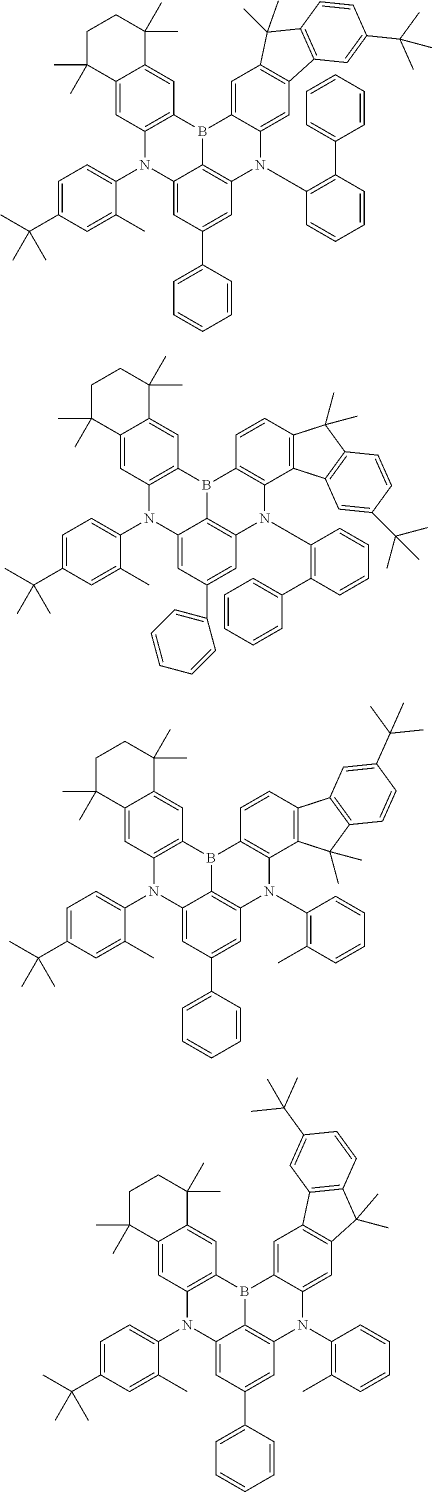

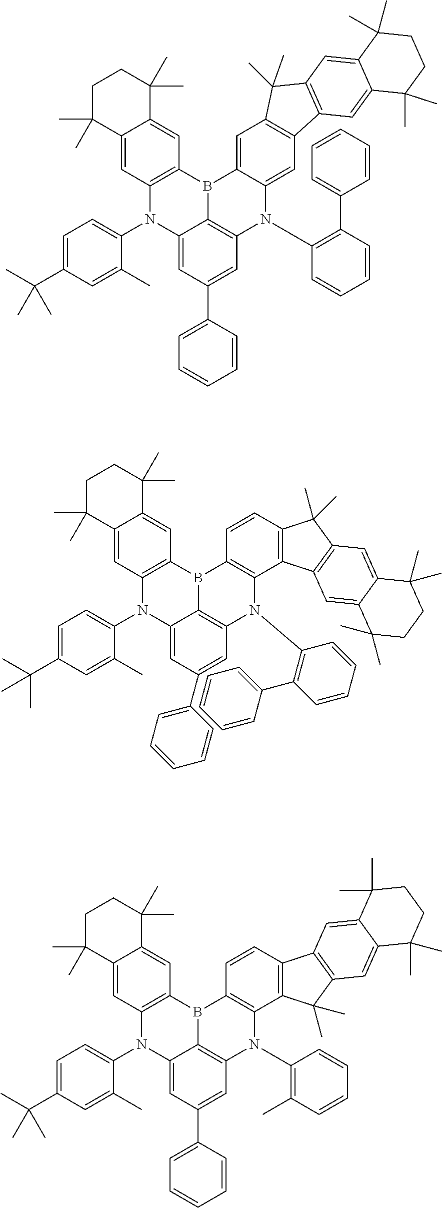

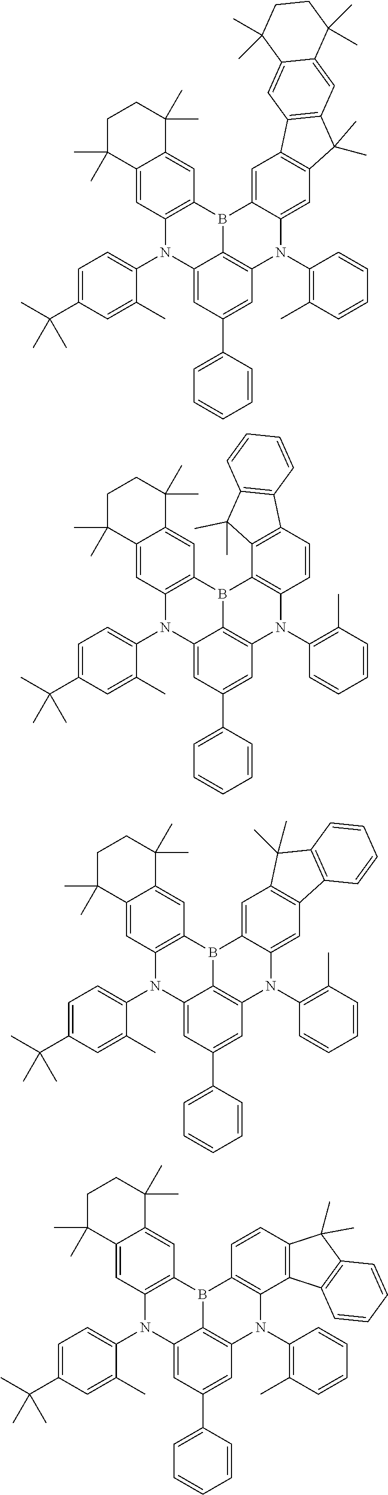

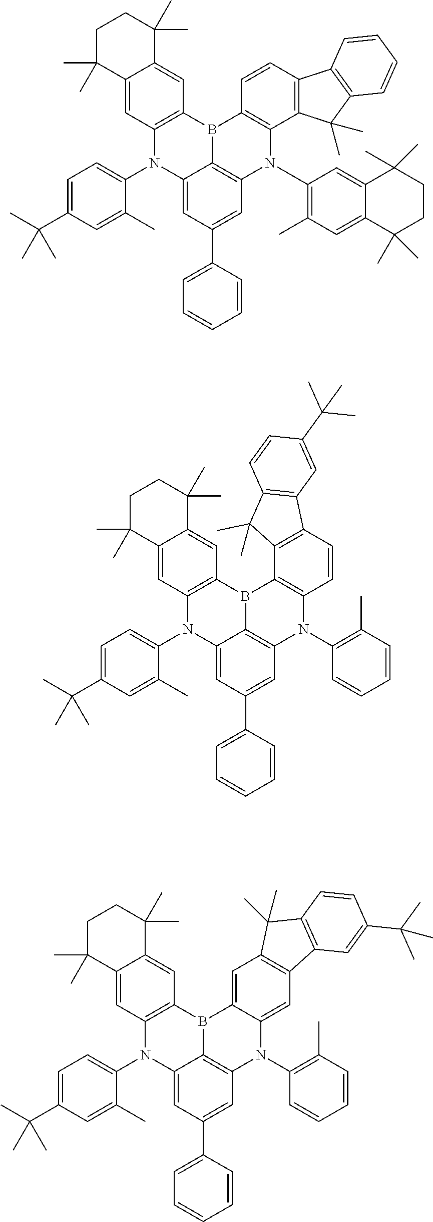 [SMILES: Cc1cc(C(C)(C)C)ccc1N1c2cc3c(cc2B2c4ccc5c(c4N(c4cc6c(cc4C)C(C)(C)CCC6(C)C)c4cc(-c6ccccc6)cc1c42)C(C)(C)c1ccccc1-5)C(C)(C)CCC3(C)C ; Cc1cc(C(C)(C)C)ccc1N1c2cc3c(cc2B2c4c1cc(-c1ccccc1)cc4N(c1ccccc1C)c1ccc4c(c12)C(C)(C)c1ccc(C(C)(C)C)cc1-4)C(C)(C)CCC3(C)C ; Cc1ccccc1N1c2cc3c(cc2B2c4cc5c(cc4N(c4ccc(C(C)(C)C)cc4C)c4cc(-c6ccccc6)cc1c42)C(C)(C)CCC5(C)C)C(C)(C)c1ccc(C(C)(C)C)cc1-3]

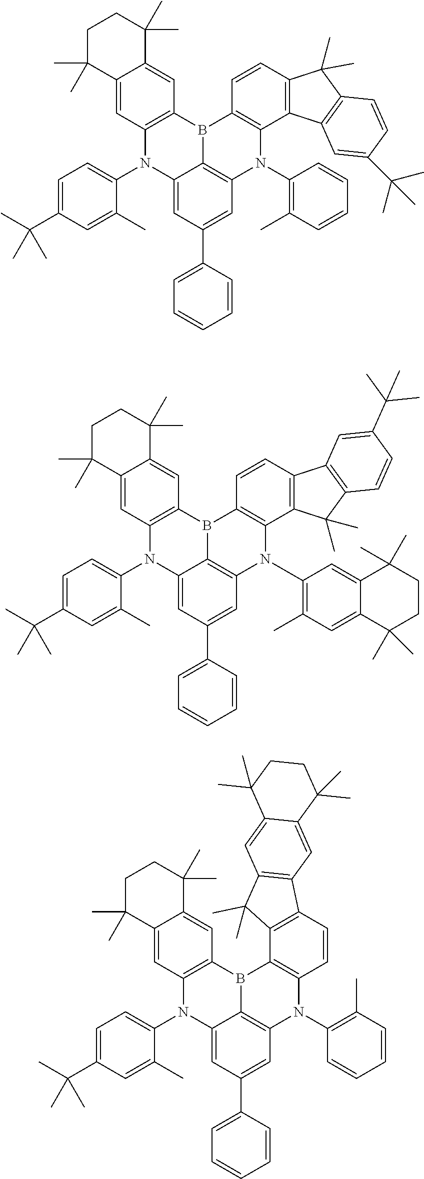

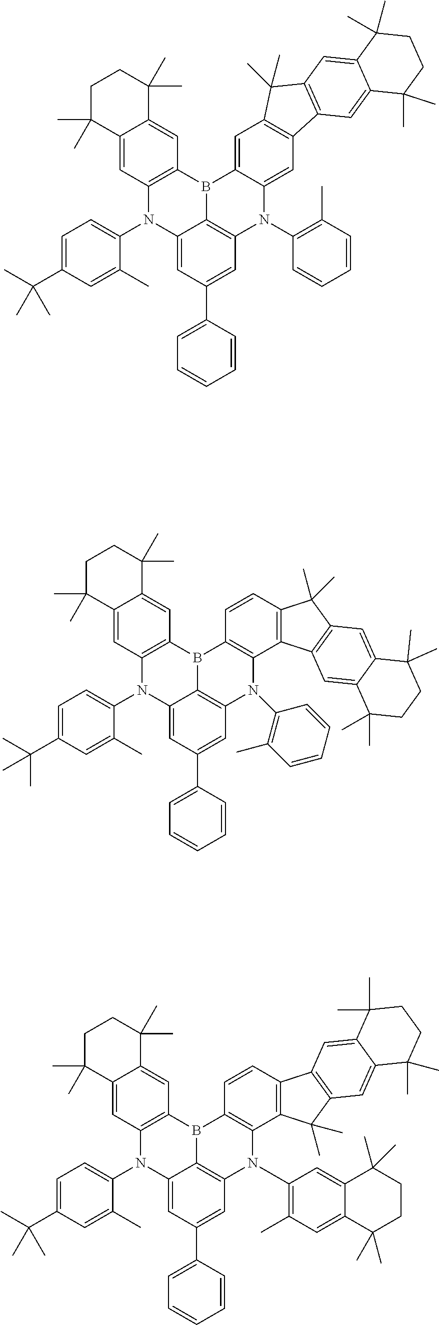

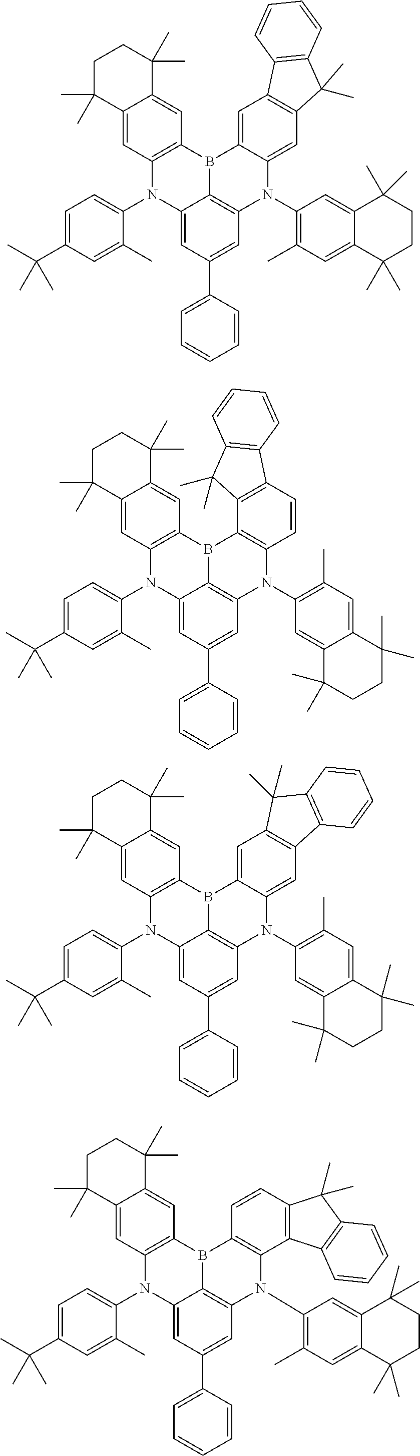

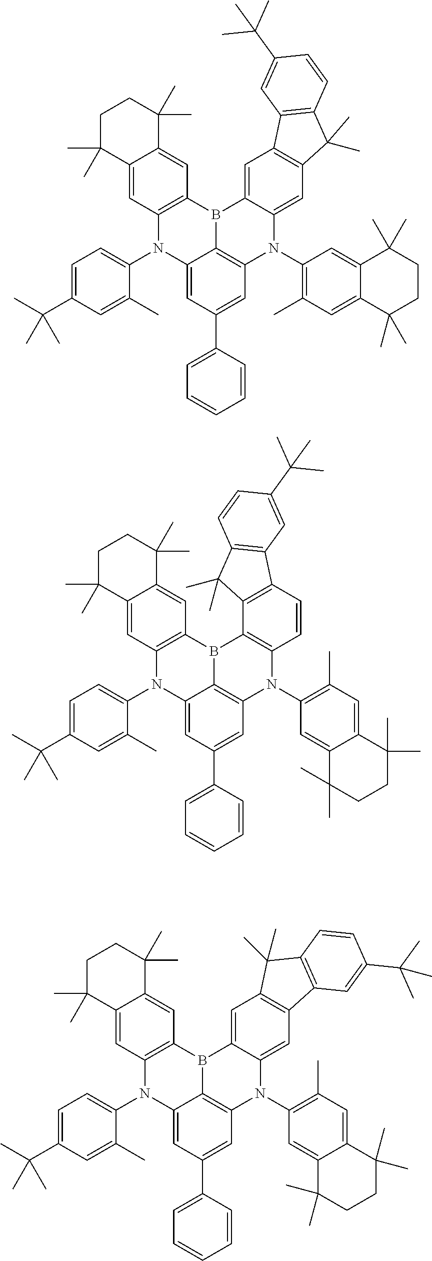

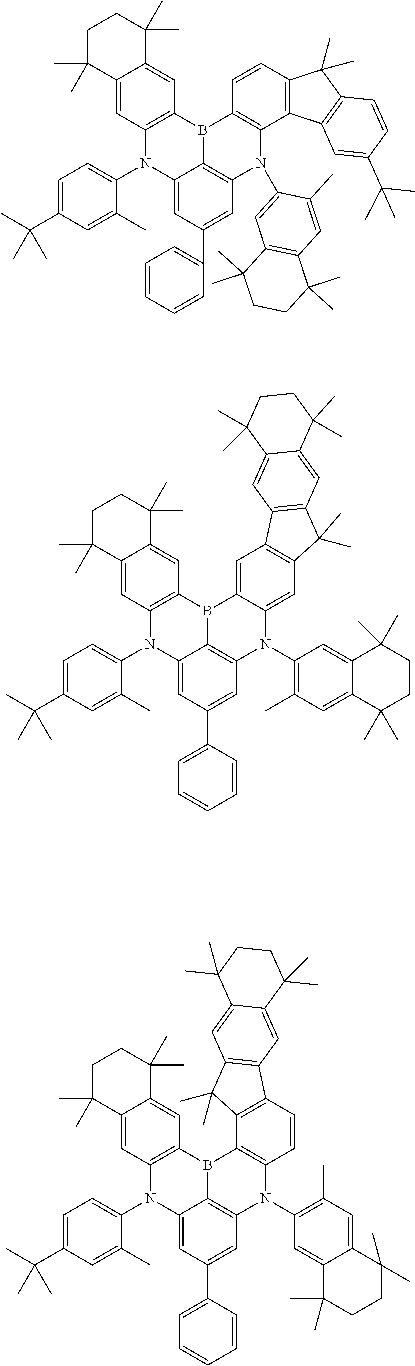

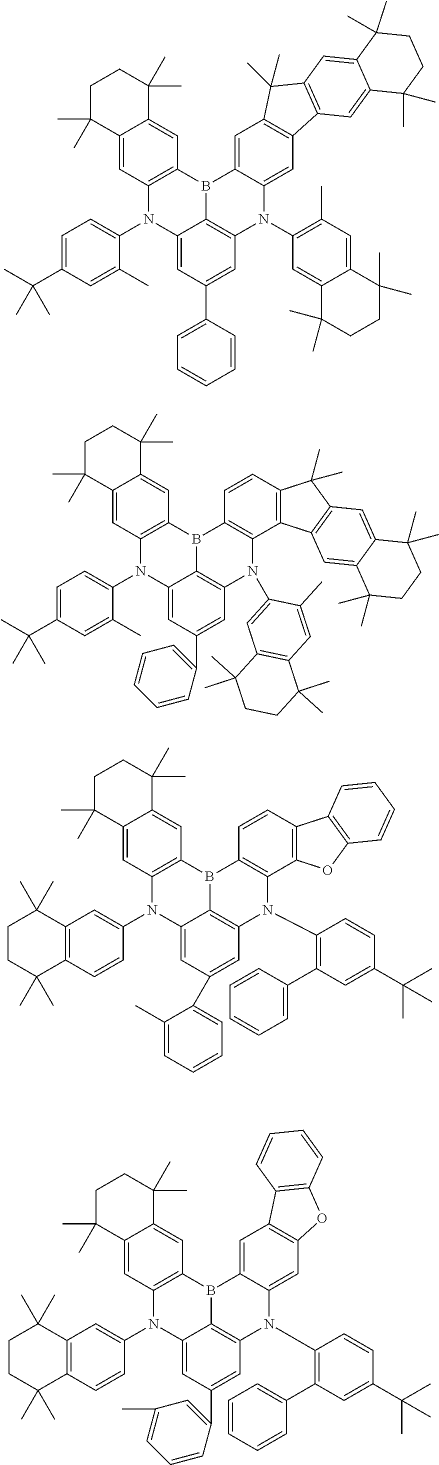

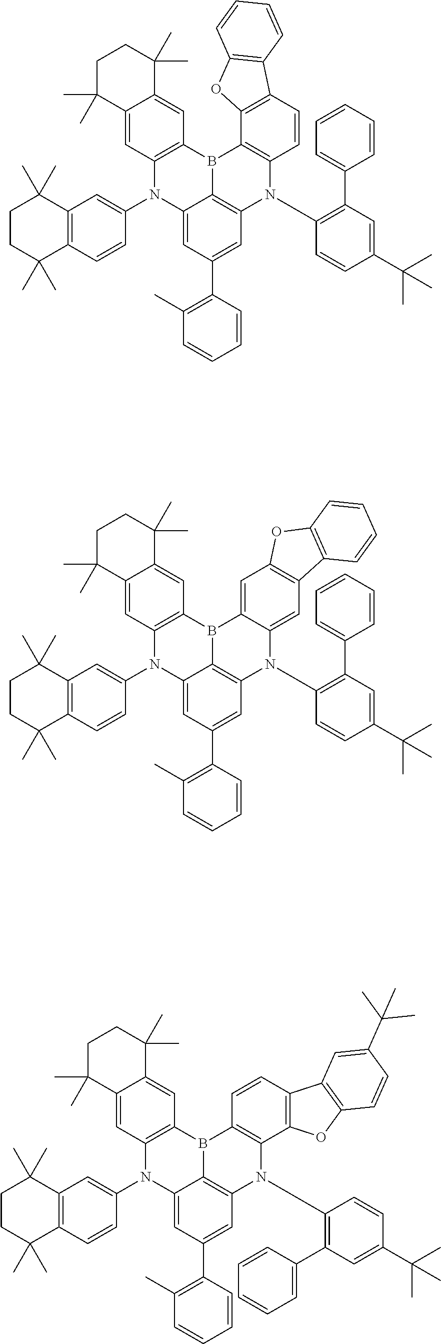 [SMILES: Cc1ccccc1-c1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1ccccc14 ; Cc1ccccc1-c1cc2c3c(c1)N(c1ccc(C(C)(C)C)cc1-c1ccccc1)c1c(ccc4c1oc1ccc(C(C)(C)C)cc14)B3c1cc3c(cc1N2c1ccc2c(c1)C(C)(C)CCC2(C)C)C(C)(C)CCC3(C)C]

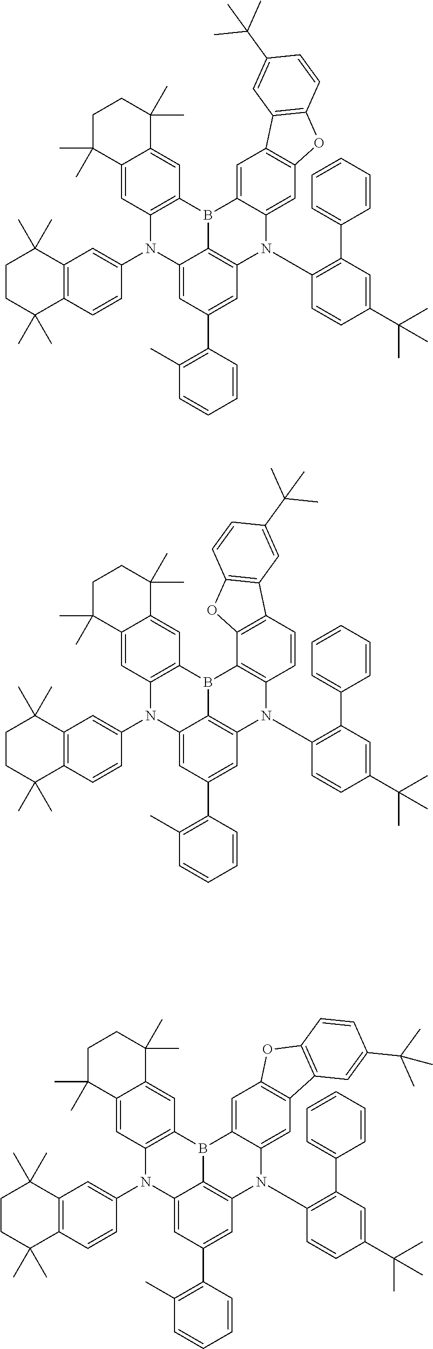 [SMILES: Cc1ccccc1-c1cc2c3c(c1)N(c1ccc(C(C)(C)C)cc1-c1ccccc1)c1cc4oc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14]

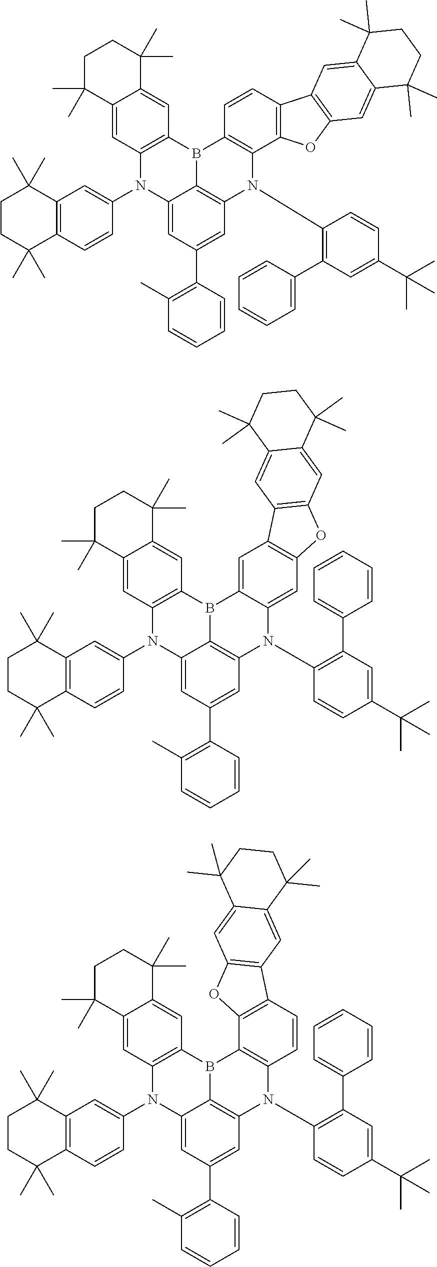

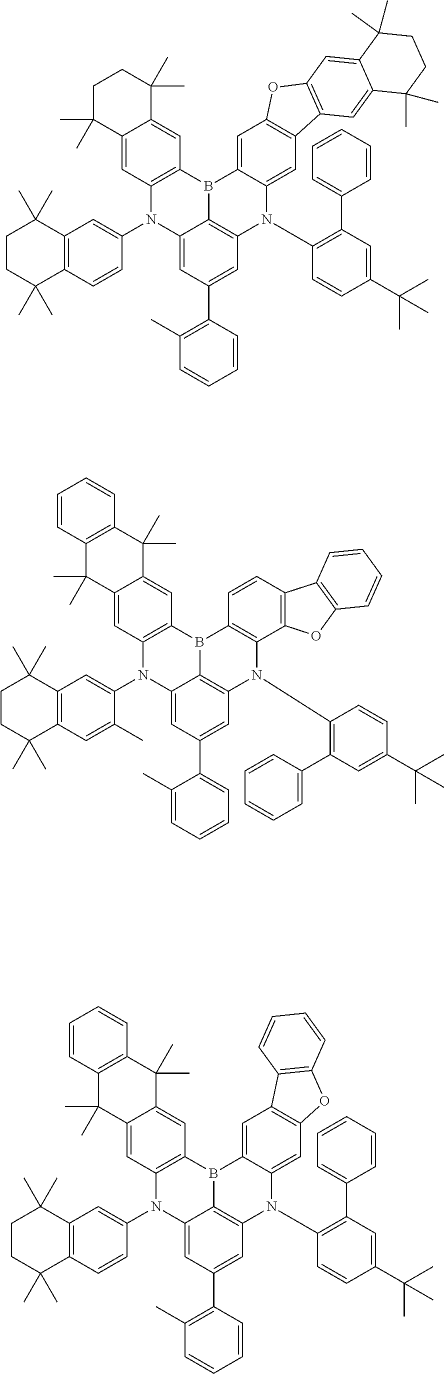 [SMILES: Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1cc2c(cc14)C(C)(C)CCC2(C)C ; Cc1ccccc1-c1cc2c3c(c1)N(c1ccc(C(C)(C)C)cc1-c1ccccc1)c1c(ccc4c1oc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)CCC2(C)C)C(C)(C)c1ccccc1C3(C)C]

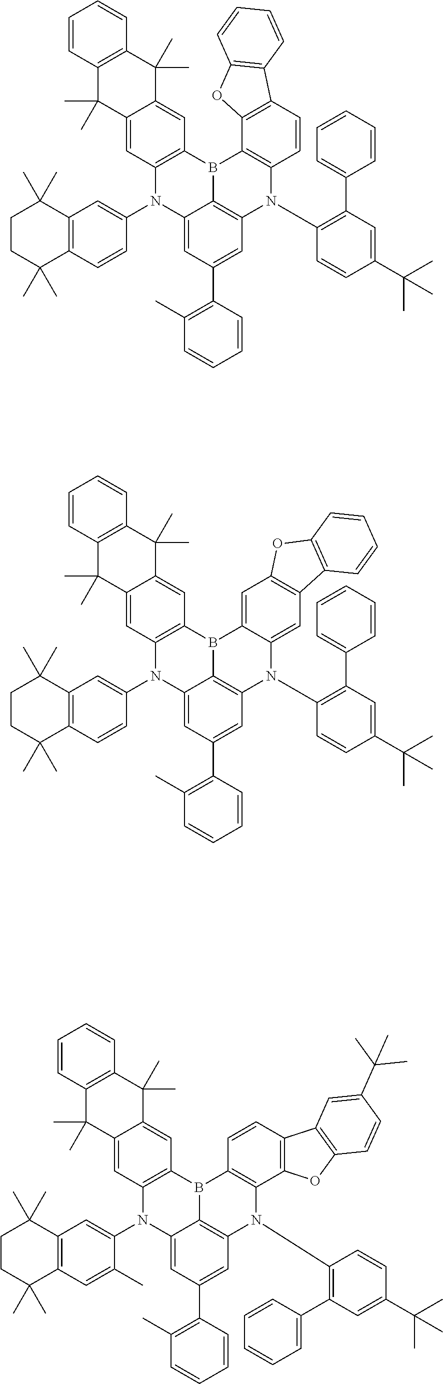 [SMILES: Cc1ccccc1-c1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)c1ccccc1C3(C)C)oc1ccccc14 ; Cc1ccccc1-c1cc2c3c(c1)N(c1ccc(C(C)(C)C)cc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C]

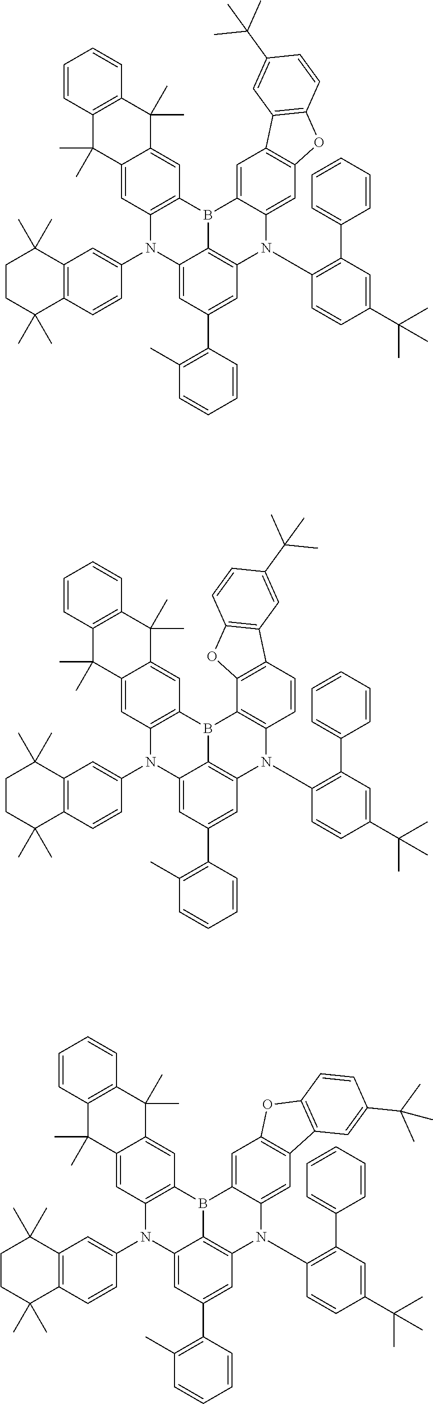 [SMILES: Cc1ccccc1-c1cc2c3c(c1)N(c1ccc(C(C)(C)C)cc1-c1ccccc1)c1cc4oc5ccc(C(C)(C)C)cc5c4cc1B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1ccc4c(oc5ccc(C(C)(C)C)cc54)c1B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)c1ccccc1C3(C)C)oc1ccc(C(C)(C)C)cc14]

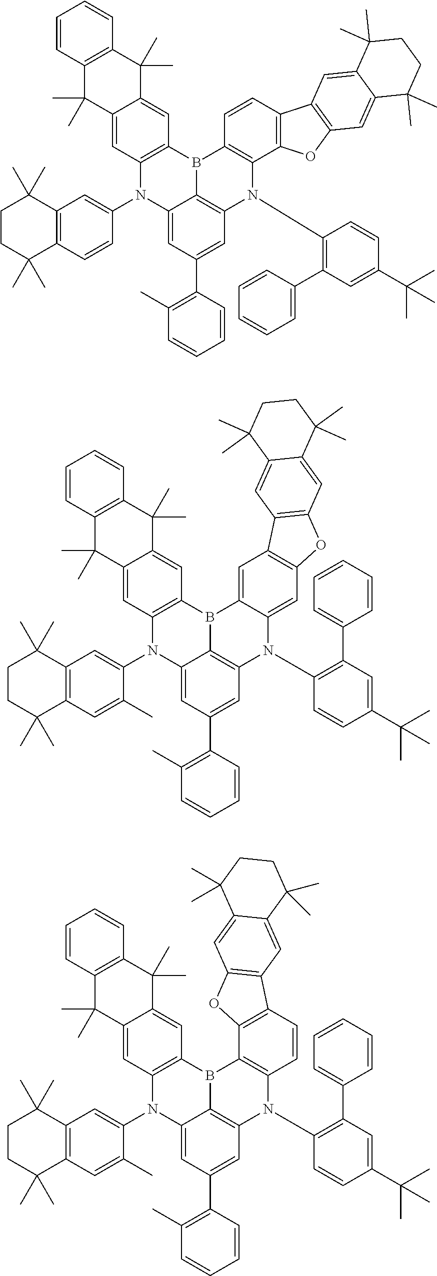 [SMILES: Cc1ccccc1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1ccccc1-c1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C]

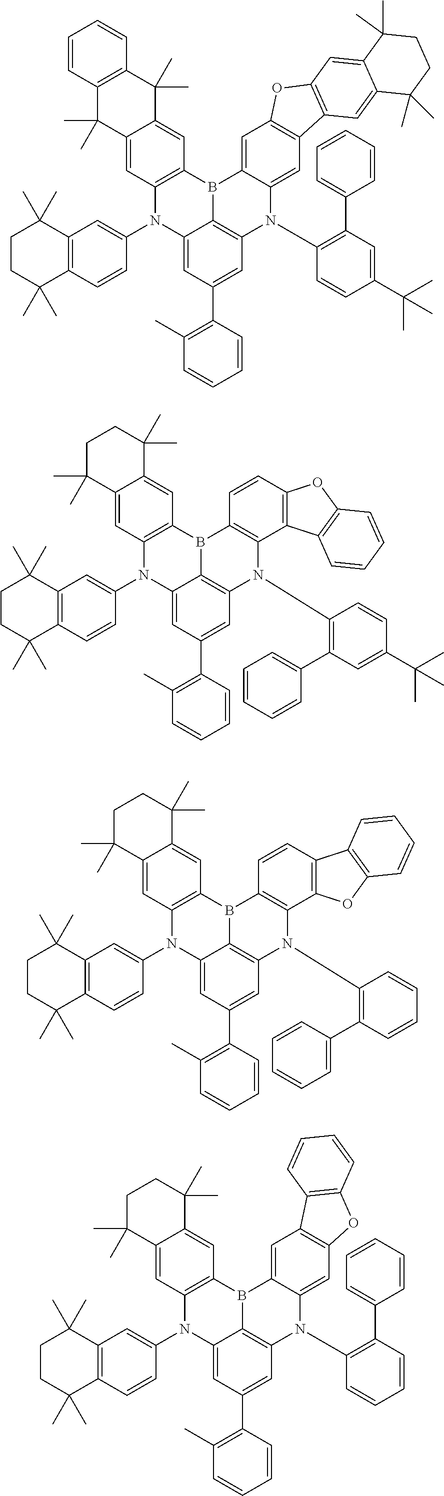

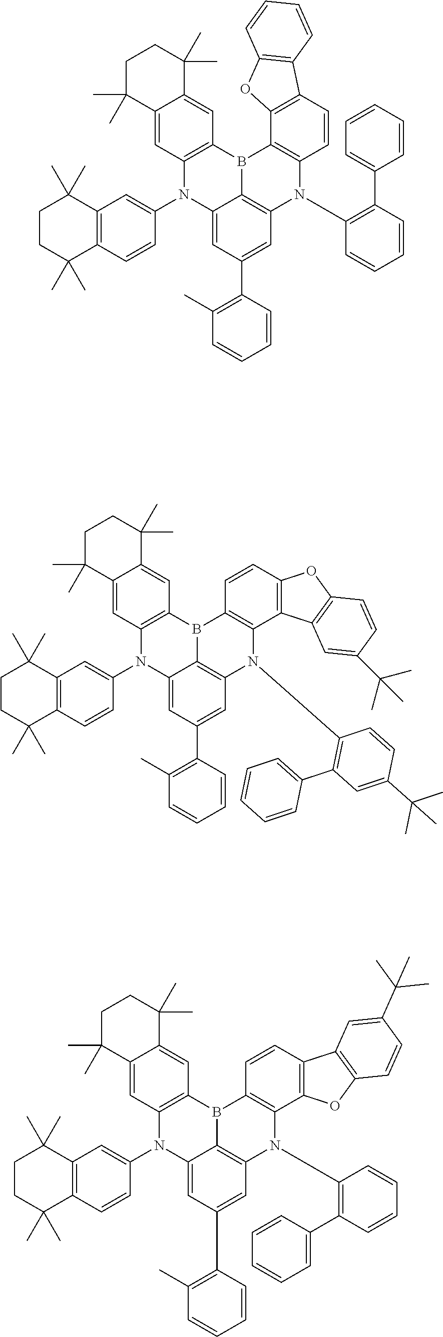 [SMILES: Cc1ccccc1-c1cc2c3c(c1)N(c1ccccc1-c1ccccc1)c1ccc4c(oc5ccccc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1oc1ccc(C(C)(C)C)cc14)B3c1cc3c(cc1N2c1ccc2c(c1)C(C)(C)CCC2(C)C)C(C)(C)CCC3(C)C]

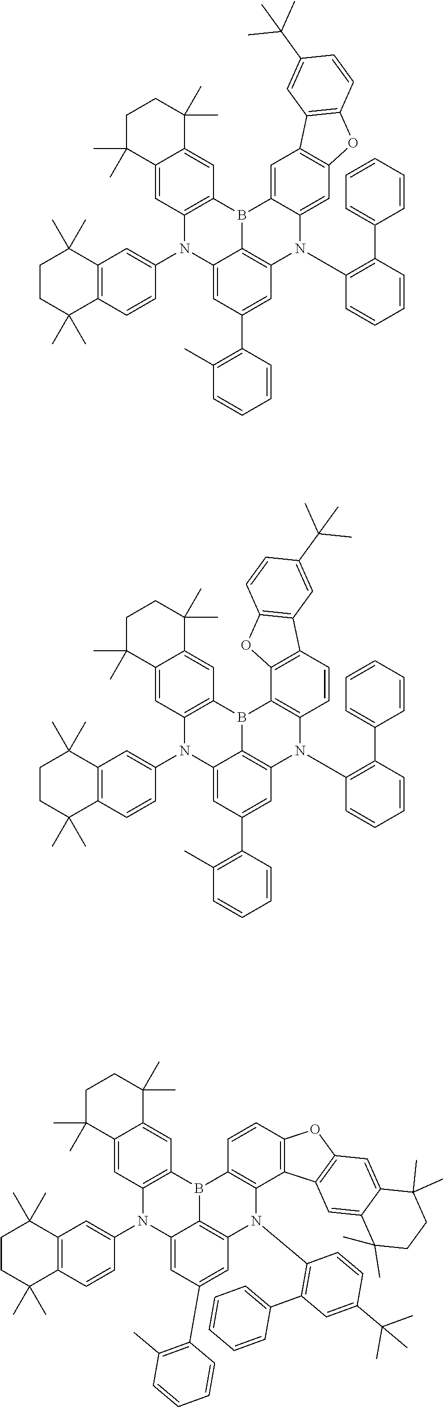 [SMILES: Cc1ccccc1-c1cc2c3c(c1)N(c1ccccc1-c1ccccc1)c1cc4oc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc2c(c1)C(C)(C)CCC2(C)C)C(C)(C)CCC3(C)C]

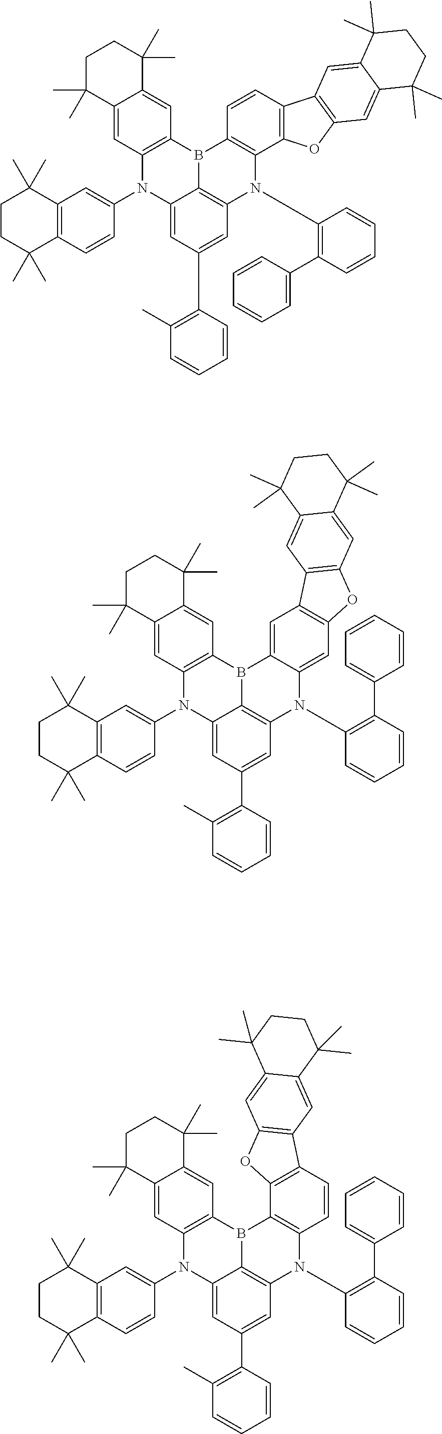 [SMILES: Cc1ccccc1-c1cc2c3c(c1)N(c1ccccc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1ccccc1-c1cc2c3c(c1)N(c1ccccc1-c1ccccc1)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C]

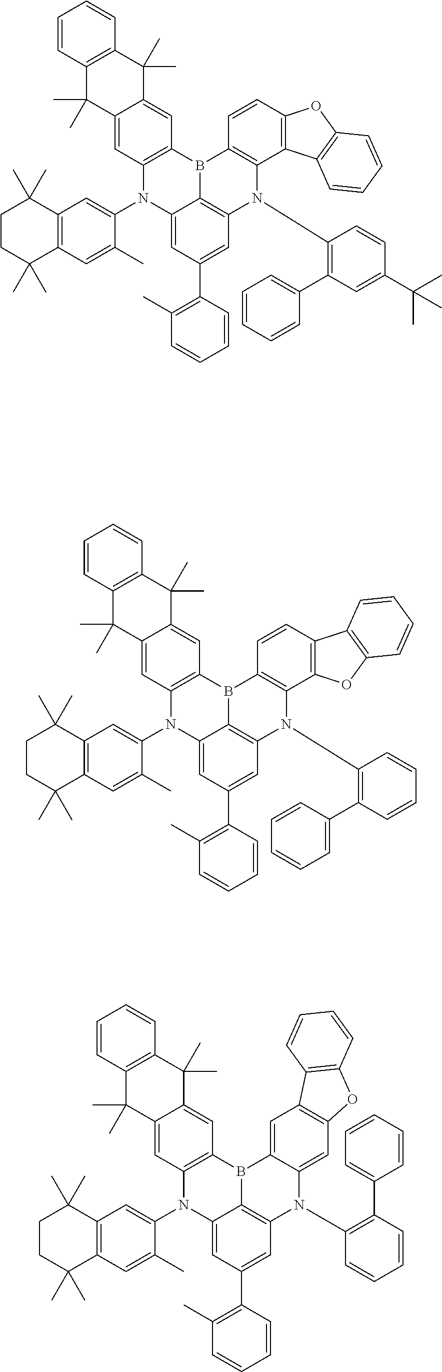 [SMILES: Cc1ccccc1-c1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1oc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4oc5ccccc5c4cc1B3c1cc3c(cc1N2c1cc2c(cc1C)C(C)(C)CCC2(C)C)C(C)(C)c1ccccc1C3(C)C]

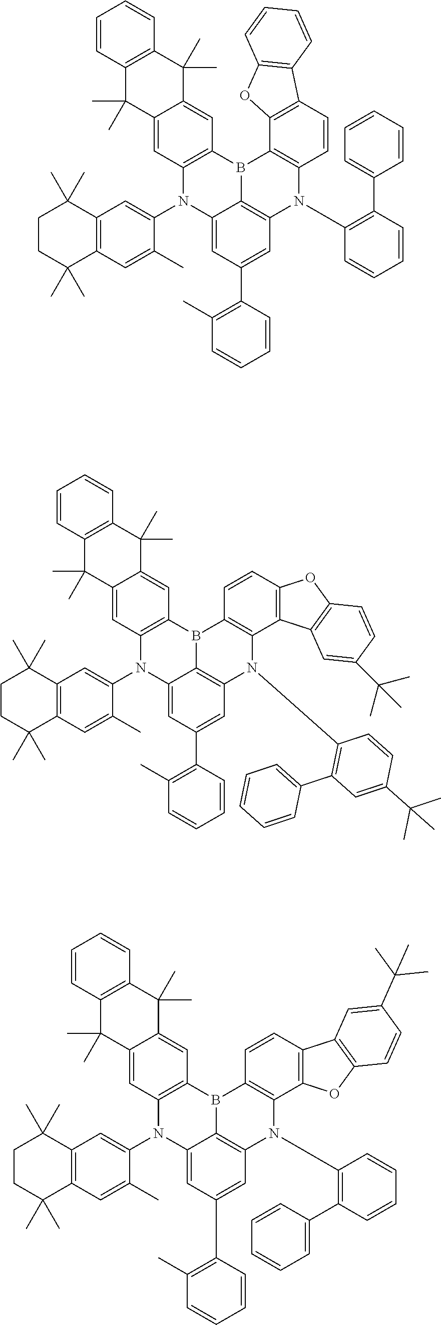 [SMILES: Cc1ccccc1-c1cc2c3c(c1)N(c1ccccc1-c1ccccc1)c1ccc4c(oc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C]

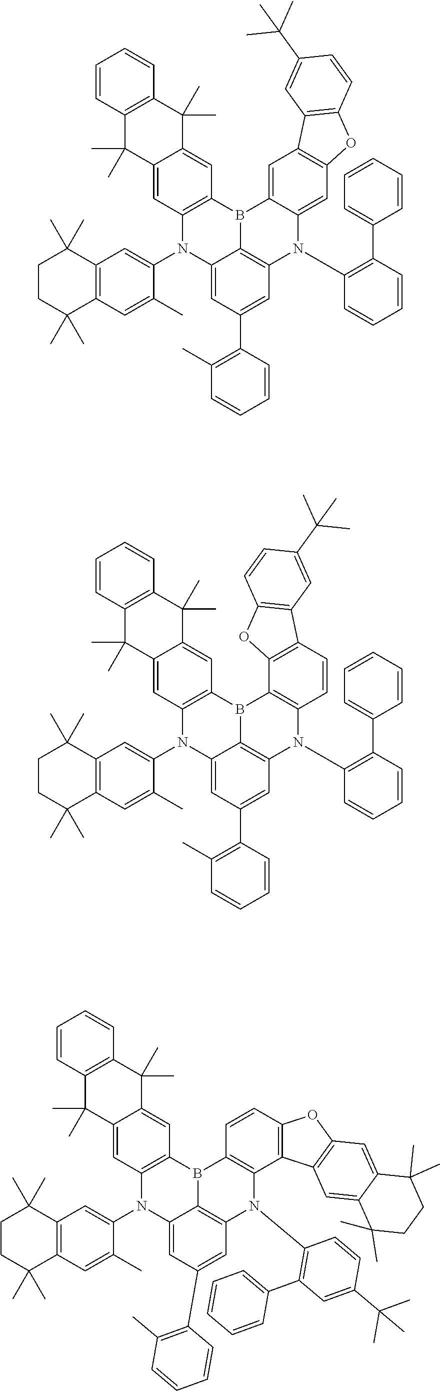 [SMILES: Cc1ccccc1-c1cc2c3c(c1)N(c1ccccc1-c1ccccc1)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C]

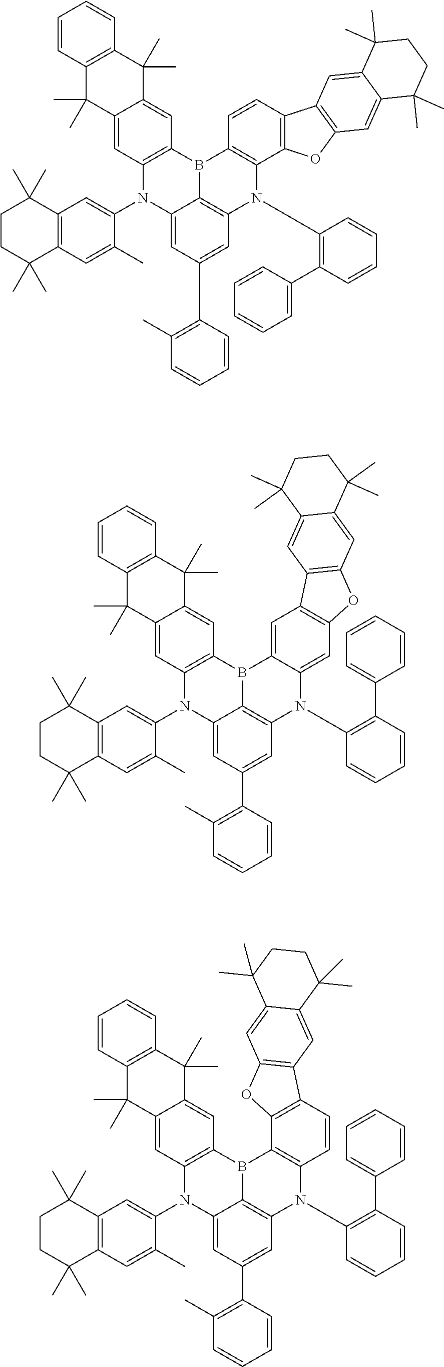 [SMILES: Cc1ccccc1-c1cc2c3c(c1)N(c1ccccc1-c1ccccc1)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1ccccc1-c1cc2c3c(c1)N(c1ccccc1-c1ccccc1)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C]

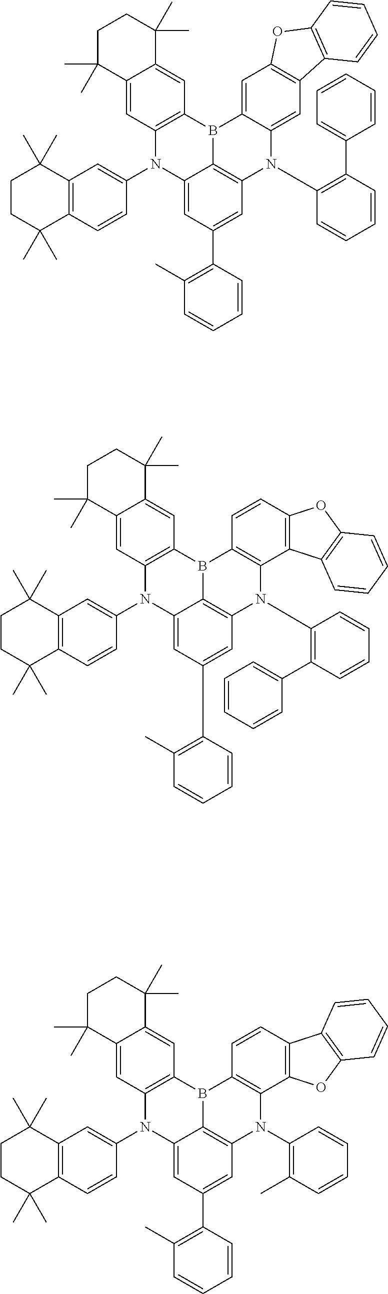 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccccc14 ; Cc1ccccc1-c1cc2c3c(c1)N(c1ccccc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1c(ccc4c1oc1ccccc14)B3c1cc3c(cc1N2c1ccc2c(c1)C(C)(C)CCC2(C)C)C(C)(C)CCC3(C)C]

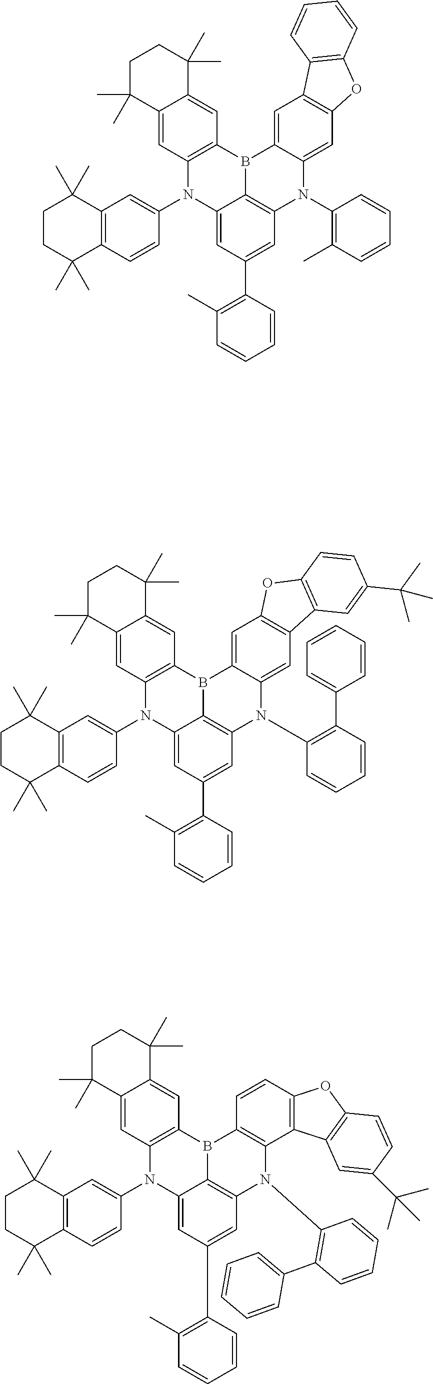 [SMILES: Cc1ccccc1-c1cc2c3c(c1)N(c1ccccc1C)c1cc4oc5ccccc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1ccccc1-c1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C]

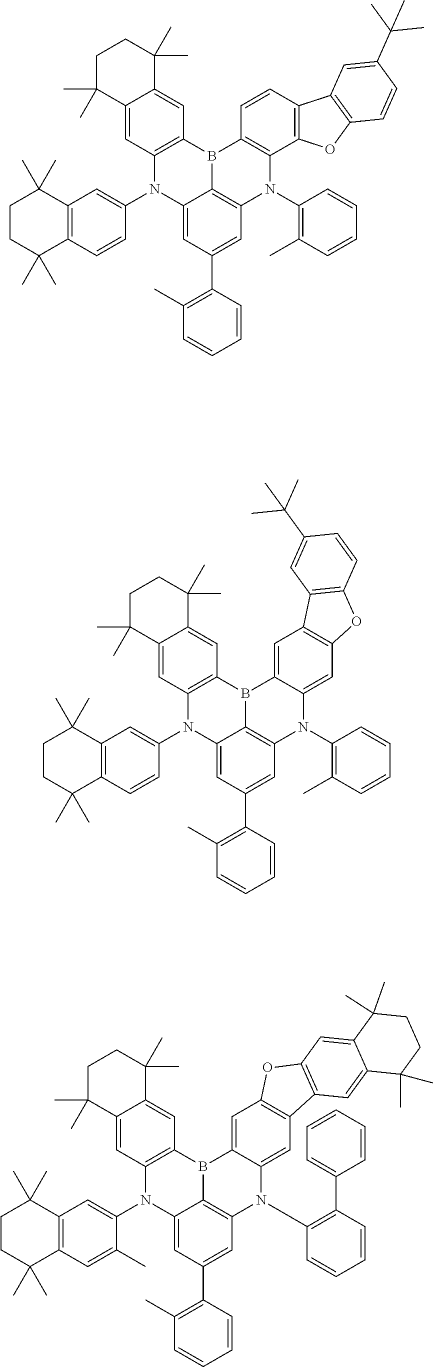 [SMILES: Cc1ccccc1-c1cc2c3c(c1)N(c1ccccc1C)c1c(ccc4c1oc1ccc(C(C)(C)C)cc14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4oc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CCC3(C)C)oc1cc2c(cc14)C(C)(C)CCC2(C)C]

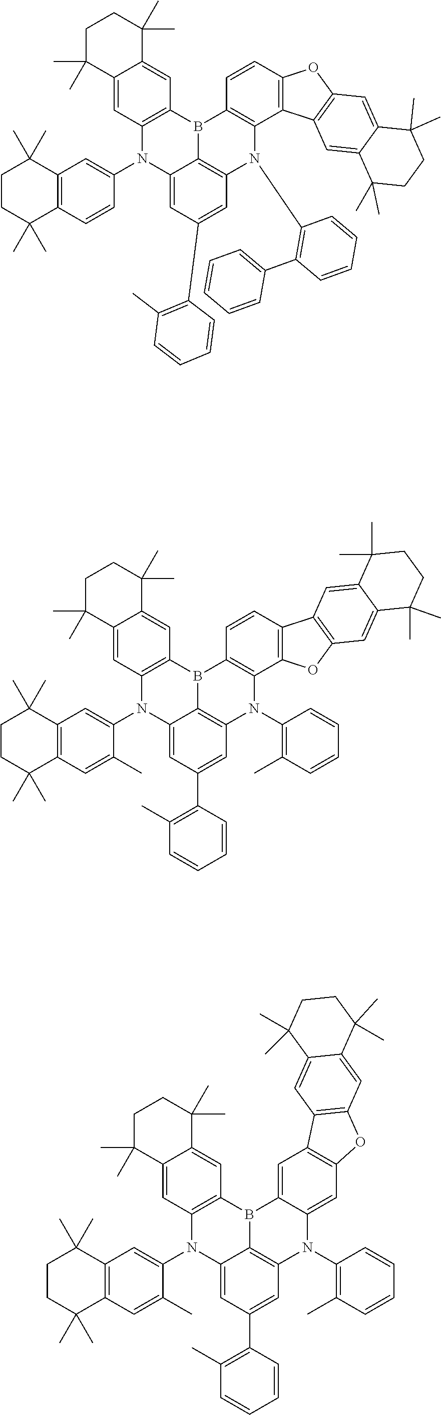 [SMILES: Cc1ccccc1-c1cc2c3c(c1)N(c1ccccc1-c1ccccc1)c1c(ccc4oc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1c(ccc4c1oc1cc5c(cc14)C(C)(C)CCC5(C)C)B3c1cc3c(cc1N2c1cc2c(cc1C)C(C)(C)CCC2(C)C)C(C)(C)CCC3(C)C ; Cc1ccccc1-c1cc2c3c(c1)N(c1ccccc1C)c1cc4oc5cc6c(cc5c4cc1B3c1cc3c(cc1N2c1cc2c(cc1C)C(C)(C)CCC2(C)C)C(C)(C)CCC3(C)C)C(C)(C)CCC6(C)C]

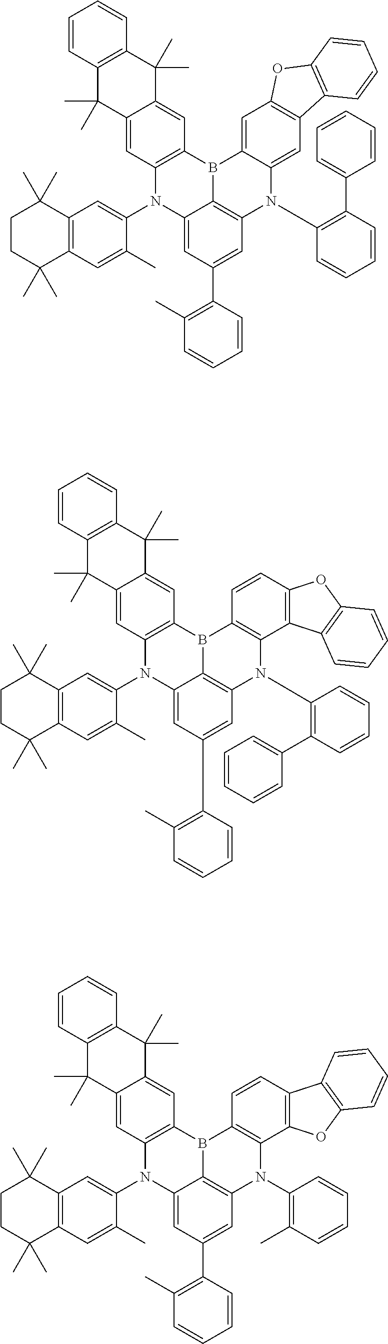 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1ccccc14 ; Cc1ccccc1-c1cc2c3c(c1)N(c1ccccc1-c1ccccc1)c1c(ccc4oc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1c(ccc4c1oc1ccccc14)B3c1cc3c(cc1N2c1cc2c(cc1C)C(C)(C)CCC2(C)C)C(C)(C)c1ccccc1C3(C)C]

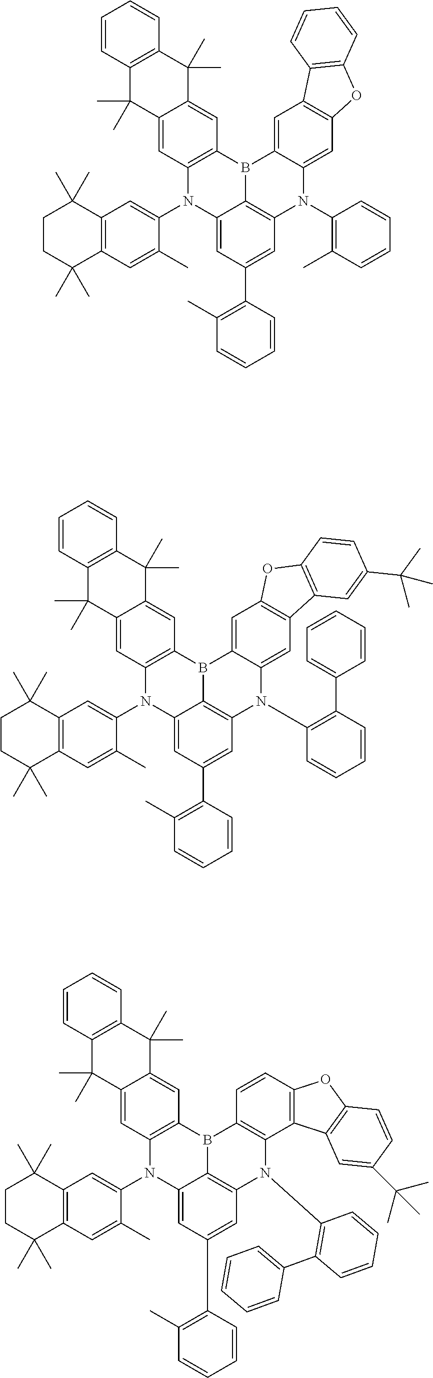 [SMILES: Cc1ccccc1-c1cc2c3c(c1)N(c1ccccc1C)c1cc4oc5ccccc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1ccccc1-c1cc2c3c(c1)N(c1ccccc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C]

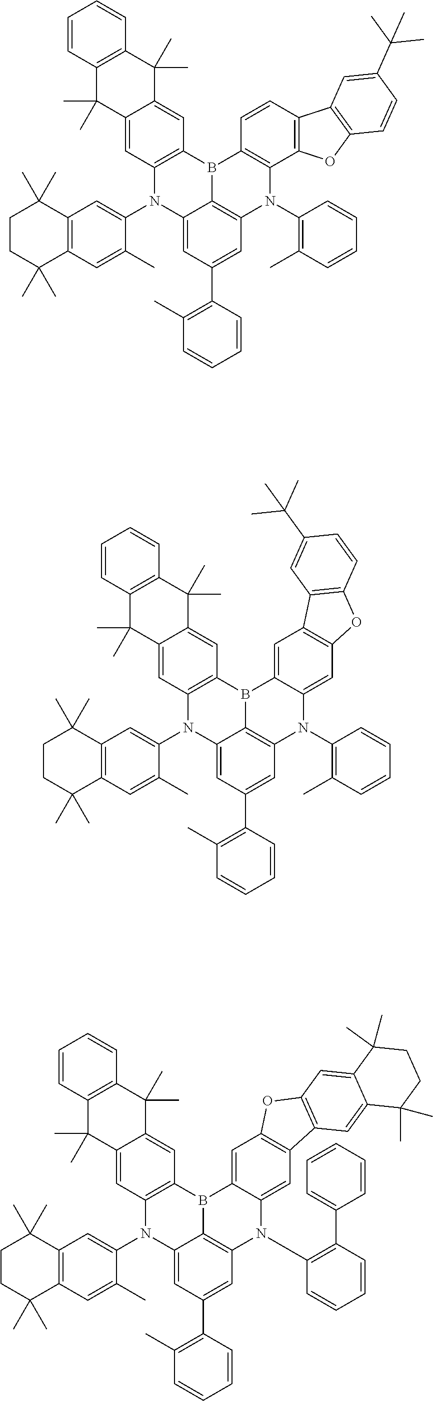 [SMILES: Cc1ccccc1-c1cc2c3c(c1)N(c1ccccc1C)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C]

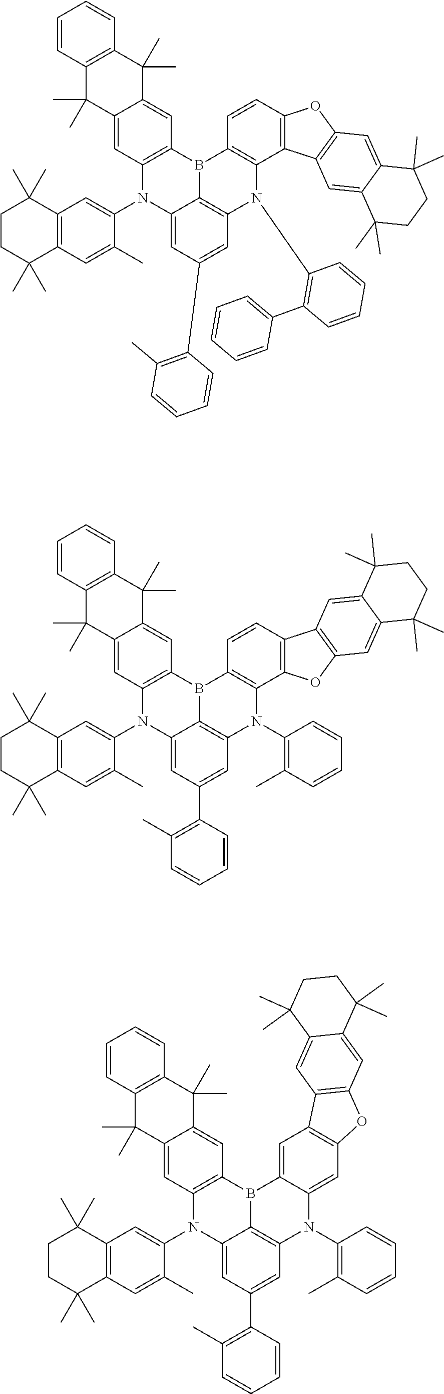 [SMILES: Cc1ccccc1-c1cc2c3c(c1)N(c1ccccc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

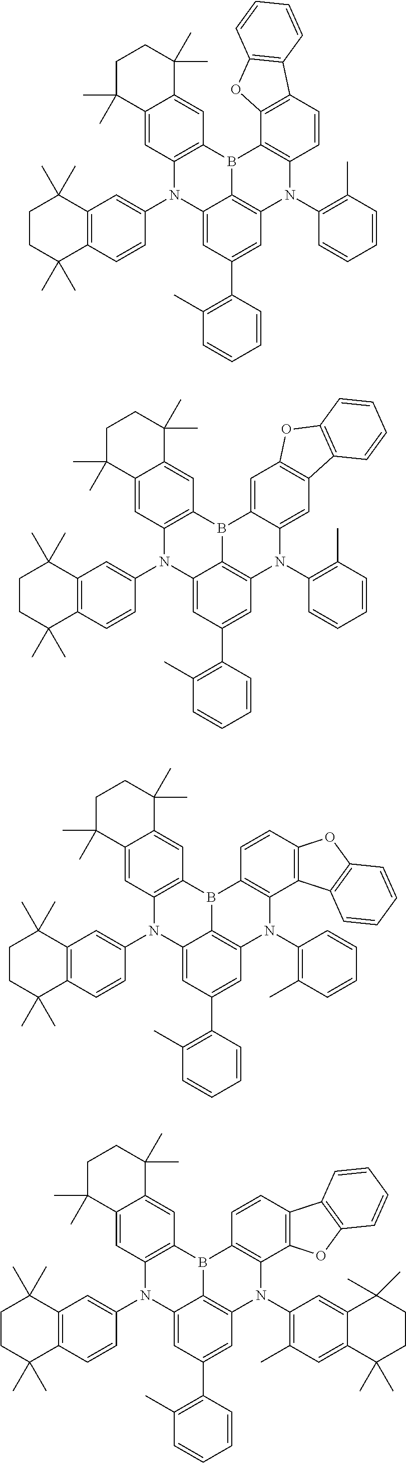 [SMILES: Cc1ccccc1-c1cc2c3c(c1)N(c1ccccc1C)c1ccc4c(oc5ccccc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1ccccc14 ; Cc1ccccc1-c1cc2c3c(c1)N(c1ccccc1C)c1c(ccc4oc5ccccc5c14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1c(ccc4c1oc1ccccc14)B3c1cc3c(cc1N2c1ccc2c(c1)C(C)(C)CCC2(C)C)C(C)(C)CCC3(C)C]

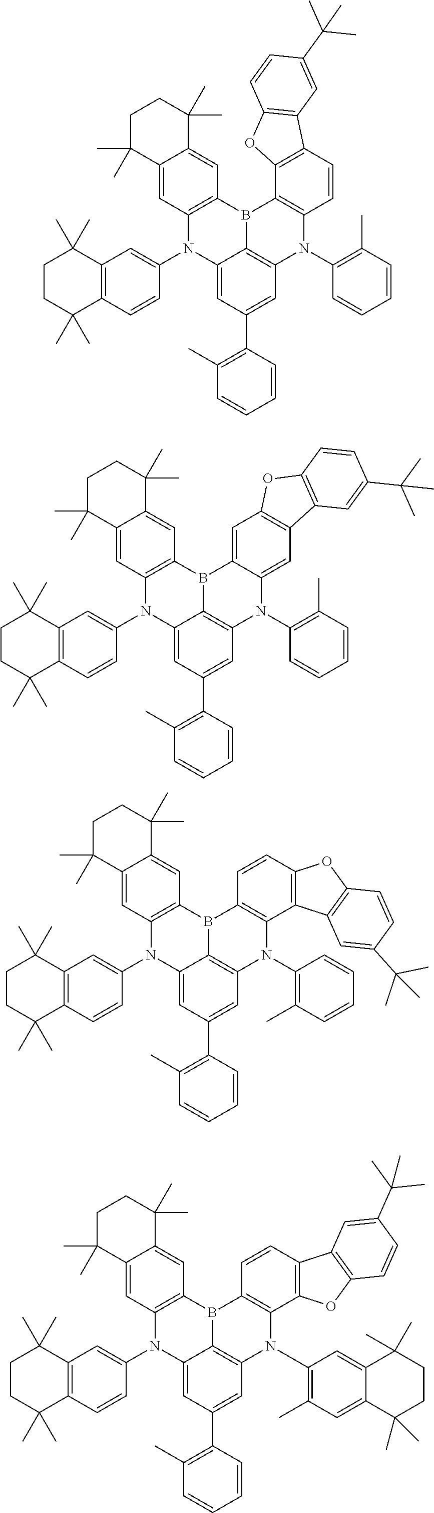

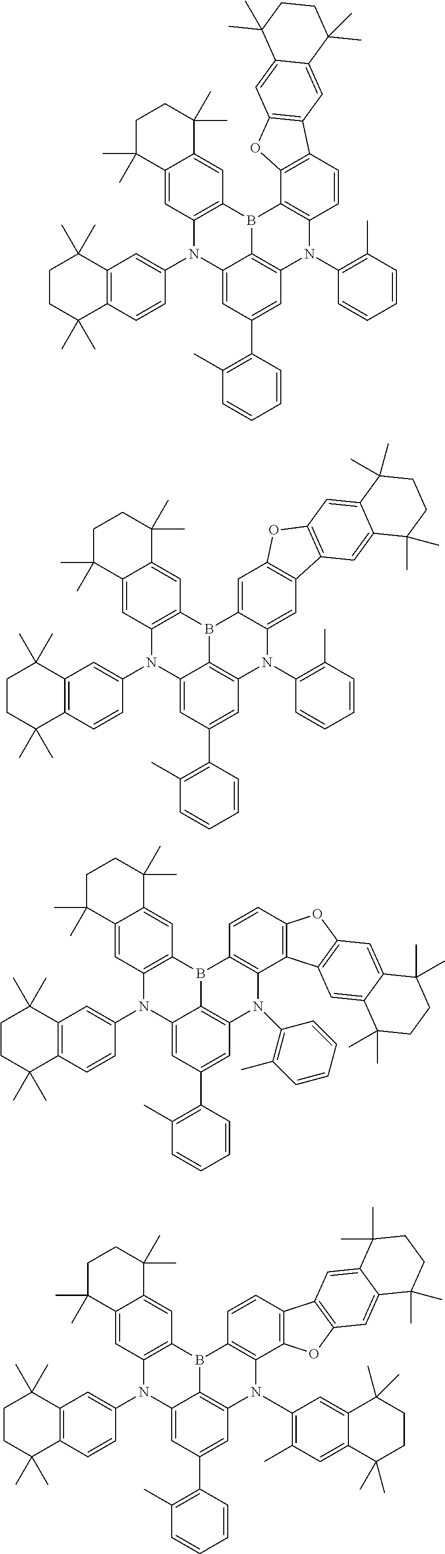

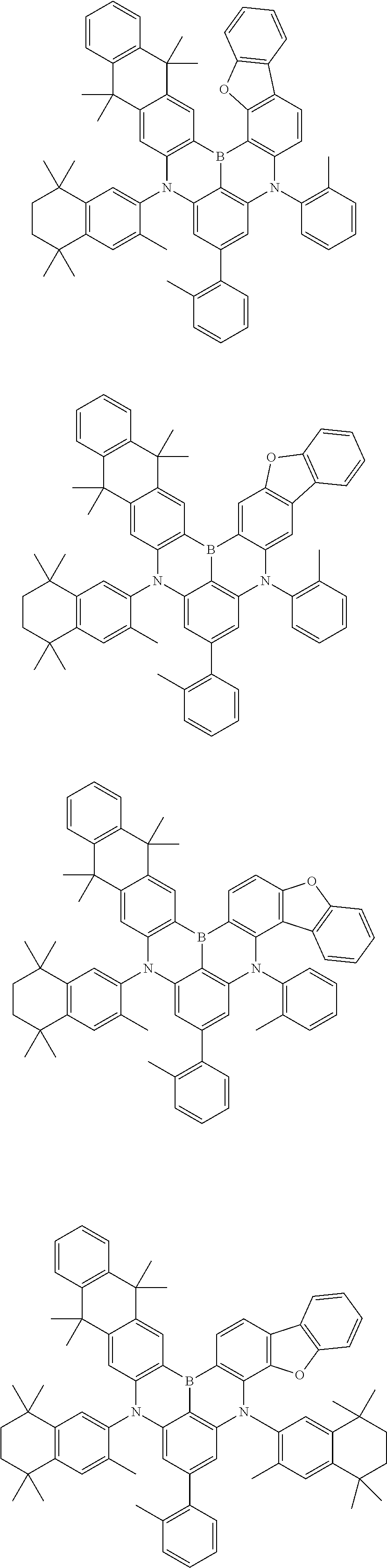 [SMILES: Cc1ccccc1-c1cc2c3c(c1)N(c1ccccc1C)c1ccc4c(oc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1ccccc14 ; Cc1ccccc1-c1cc2c3c(c1)N(c1ccccc1C)c1c(ccc4oc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)c1ccccc1C3(C)C]

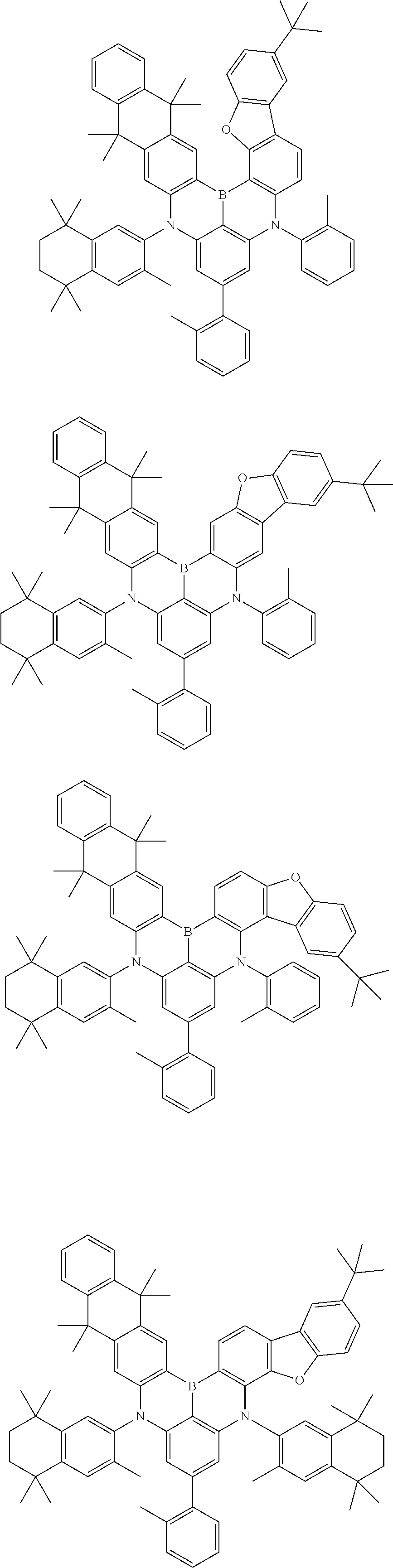

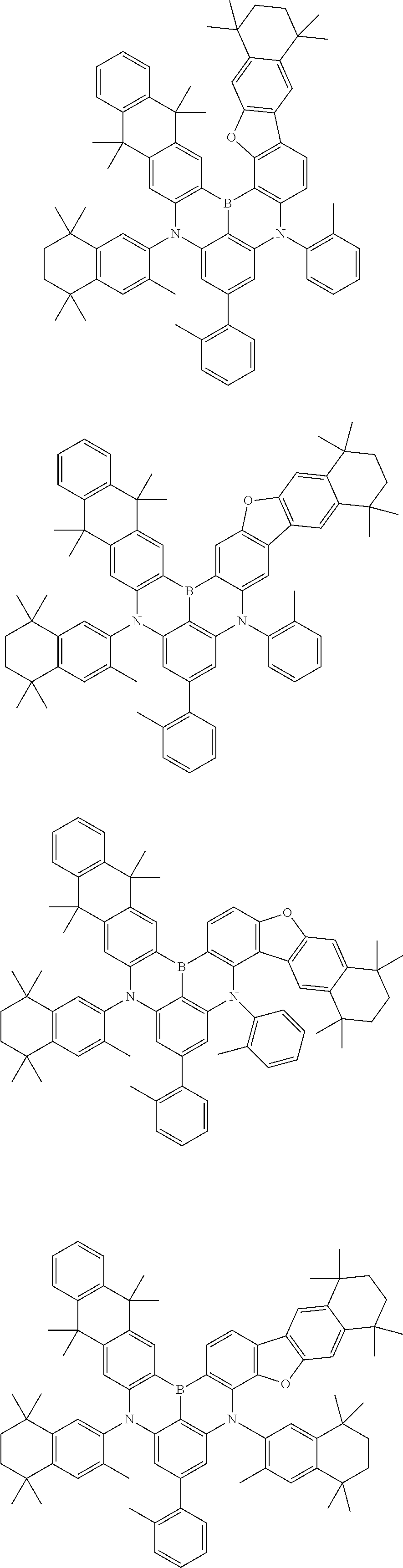

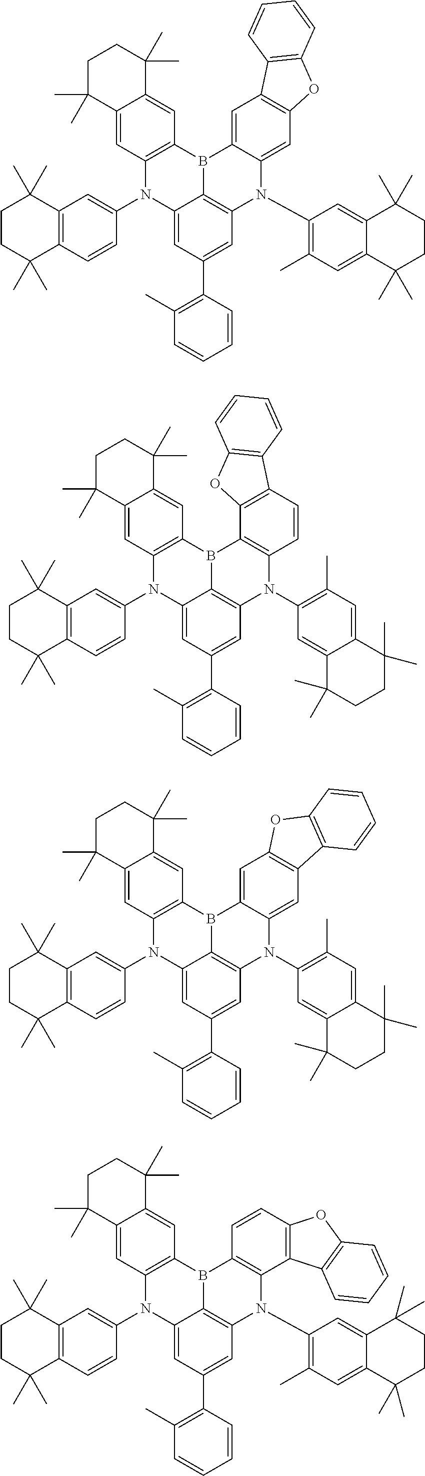

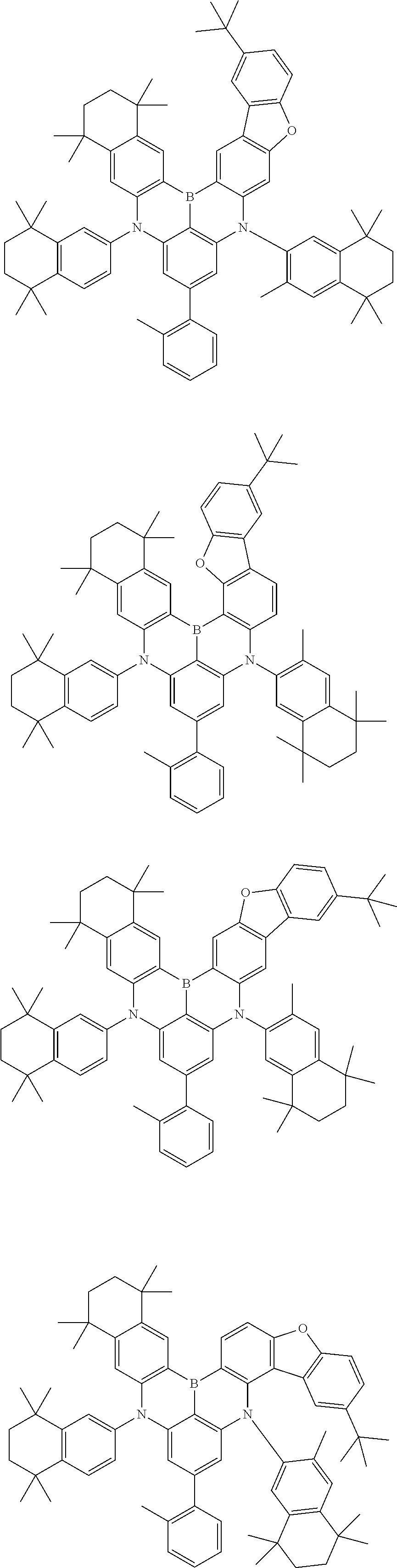

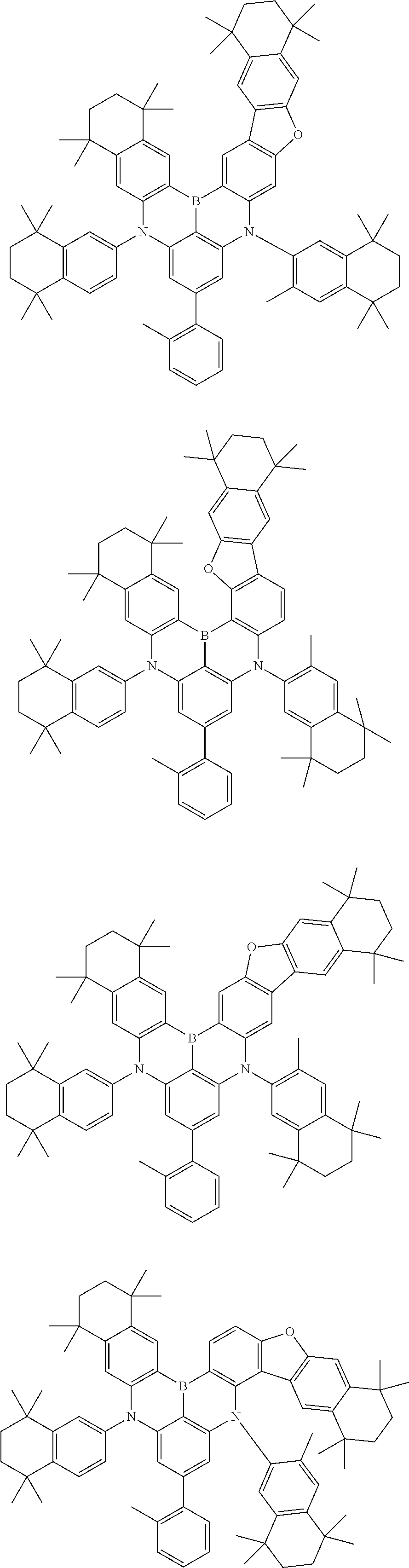

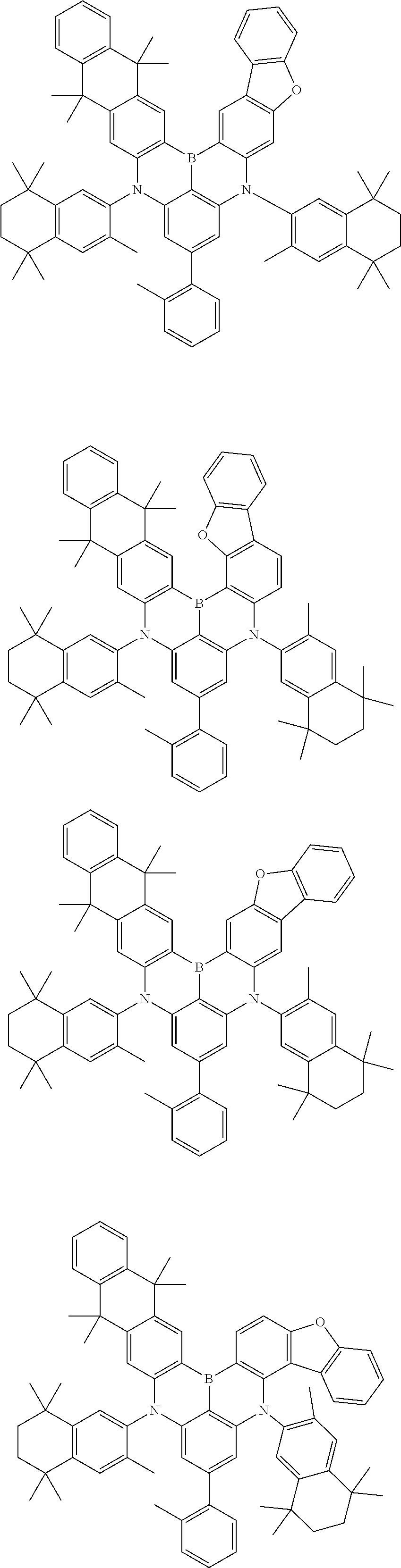

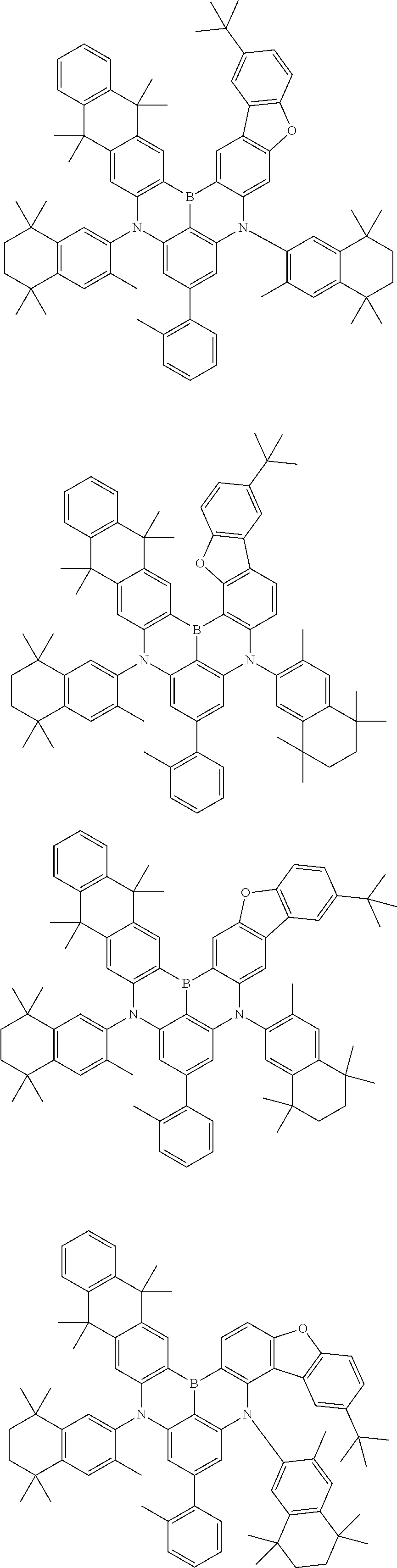

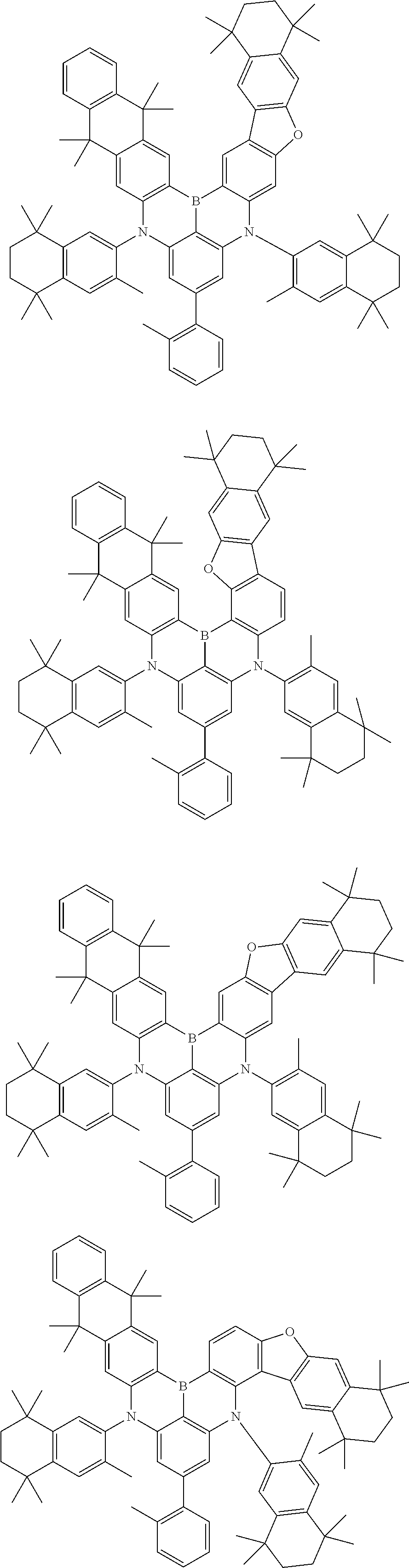

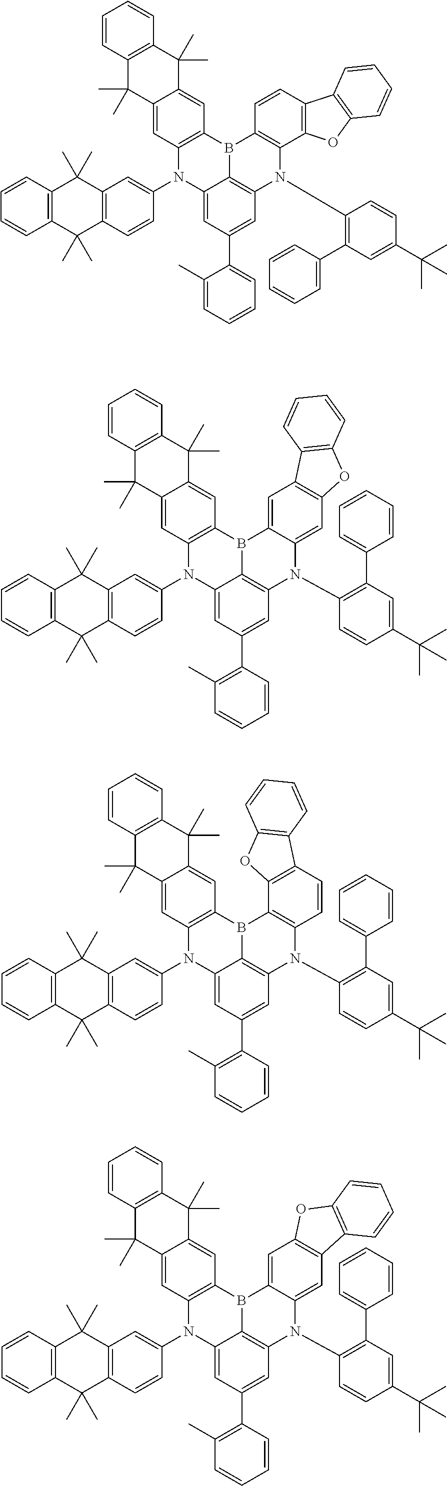

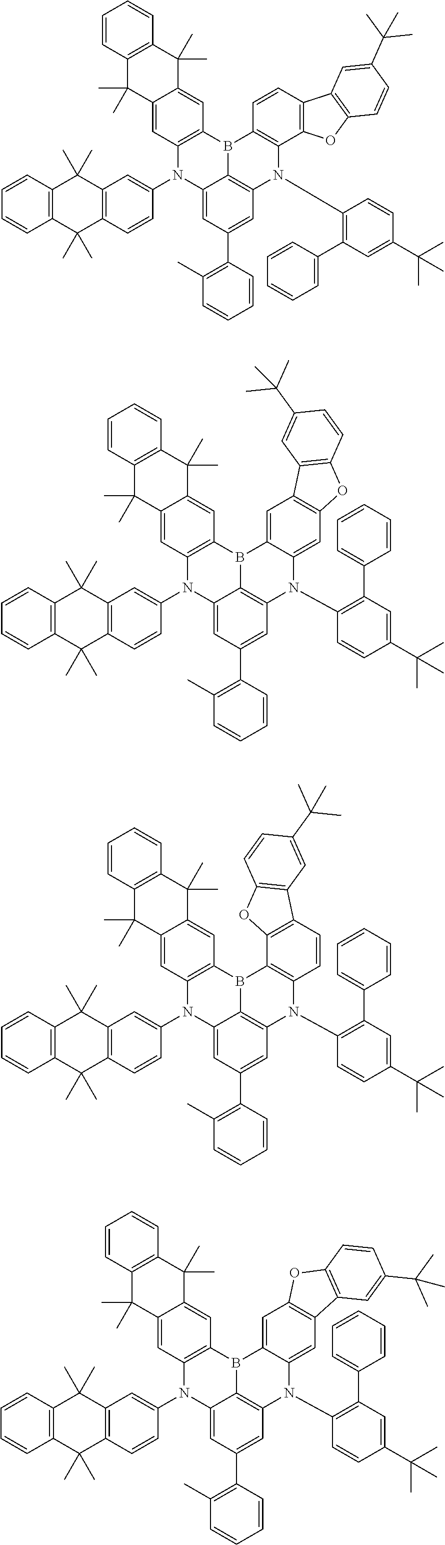

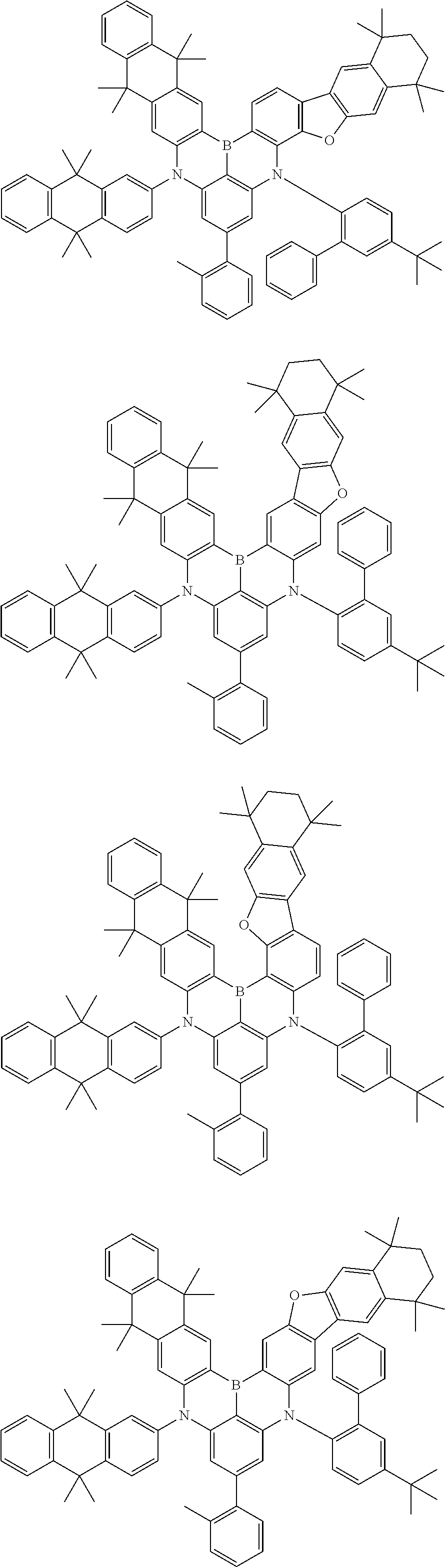

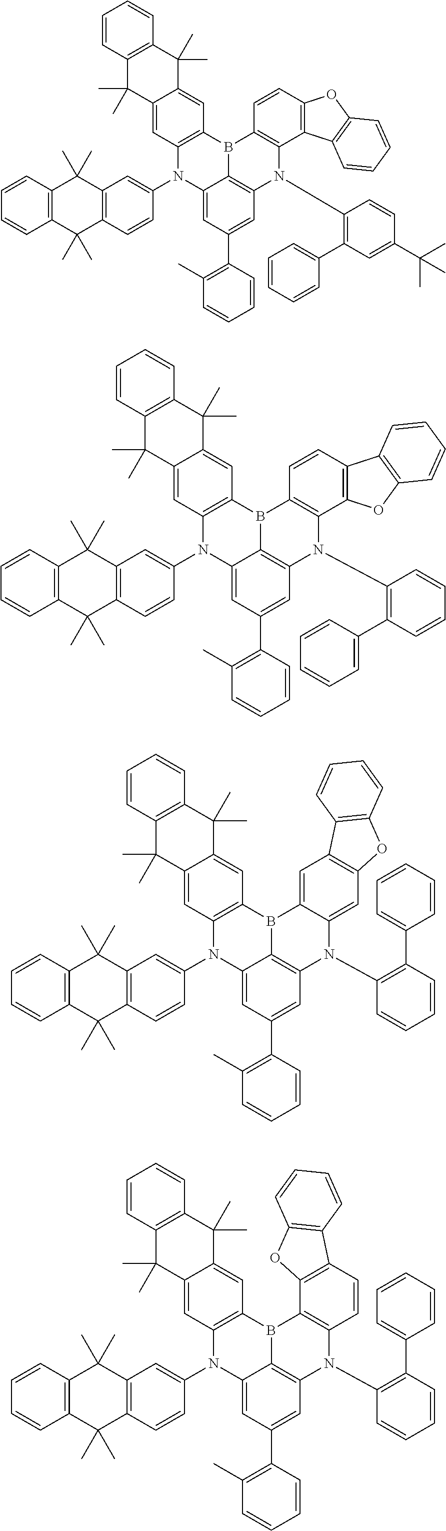

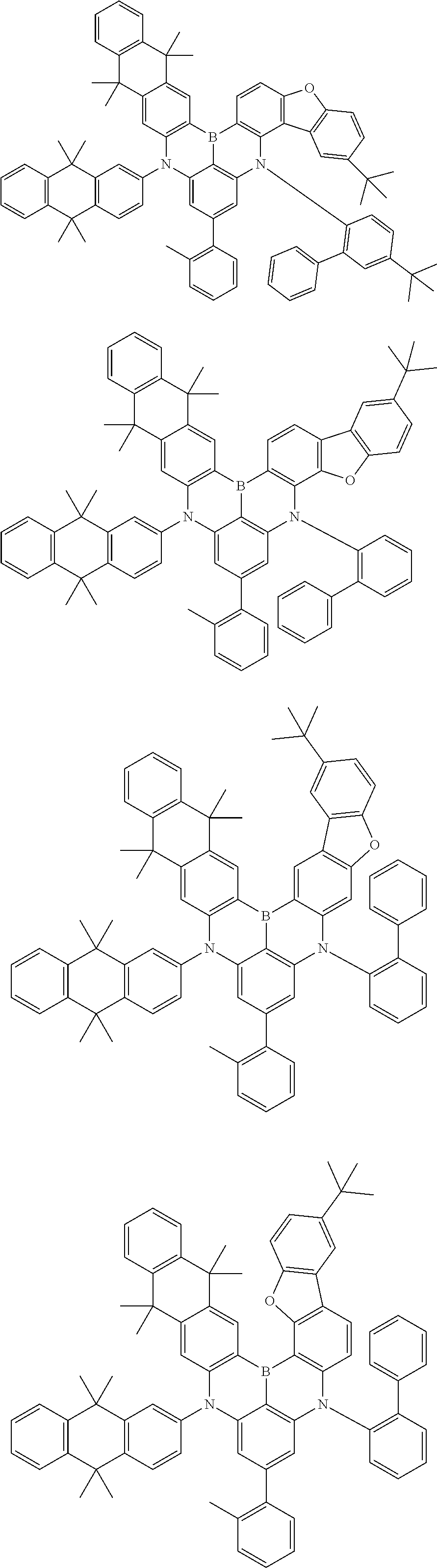

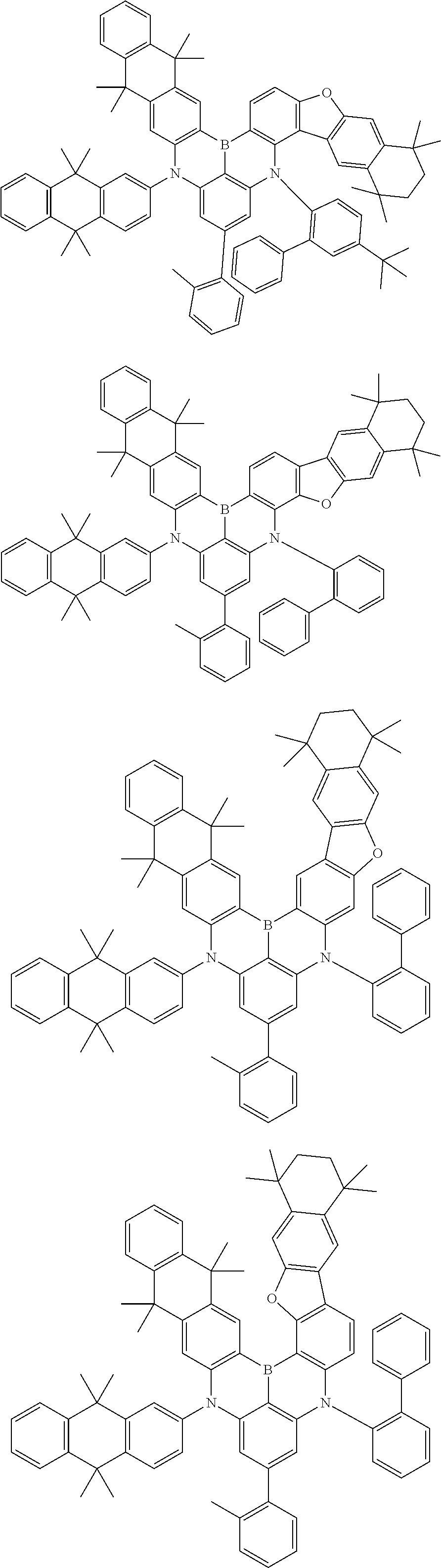

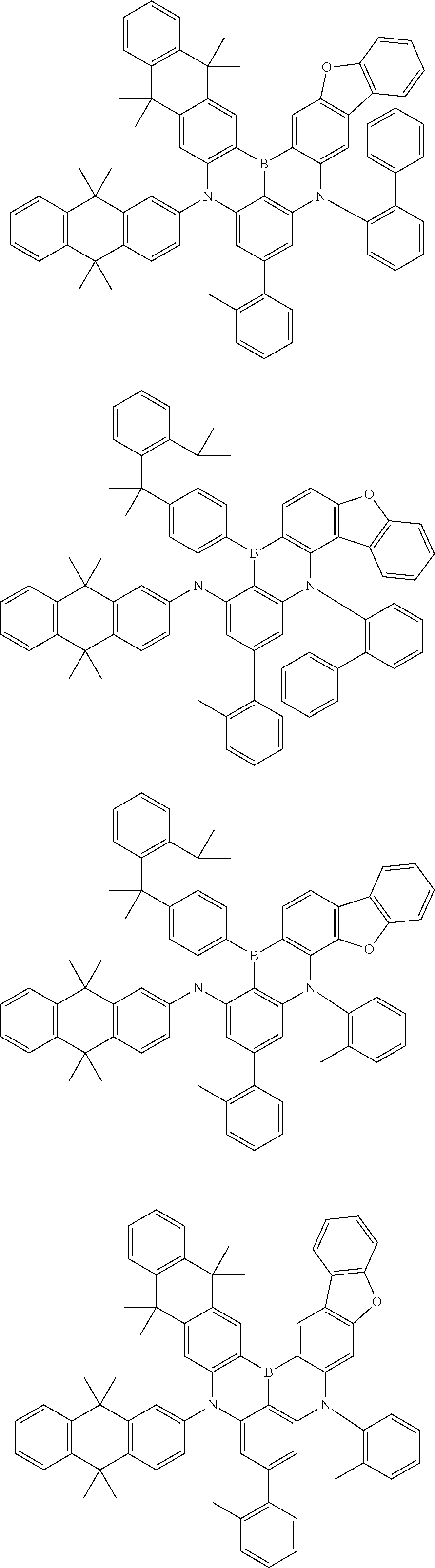

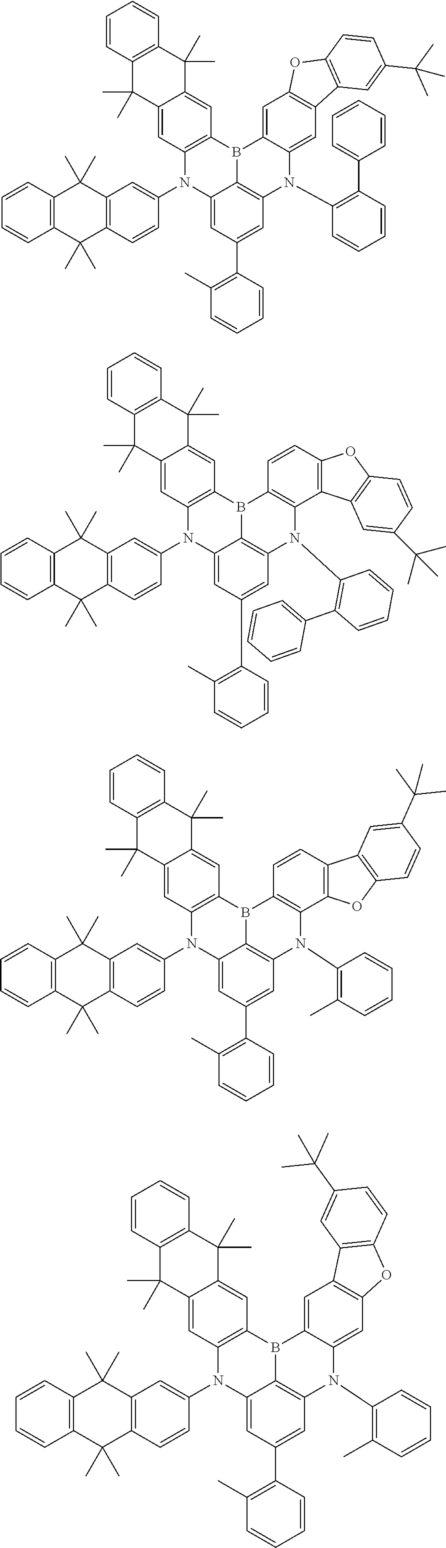

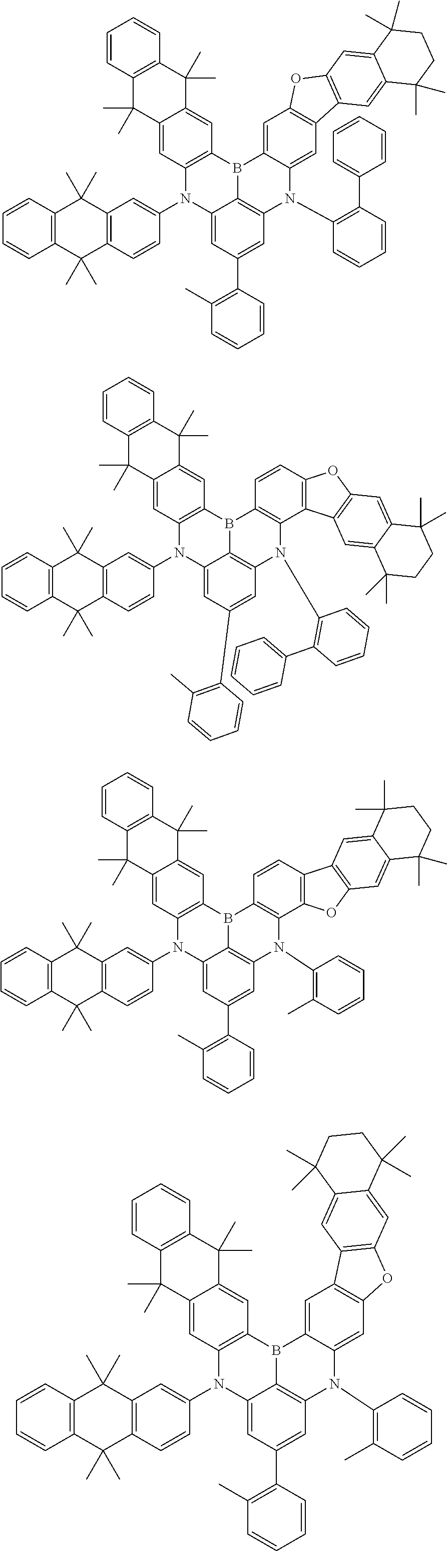

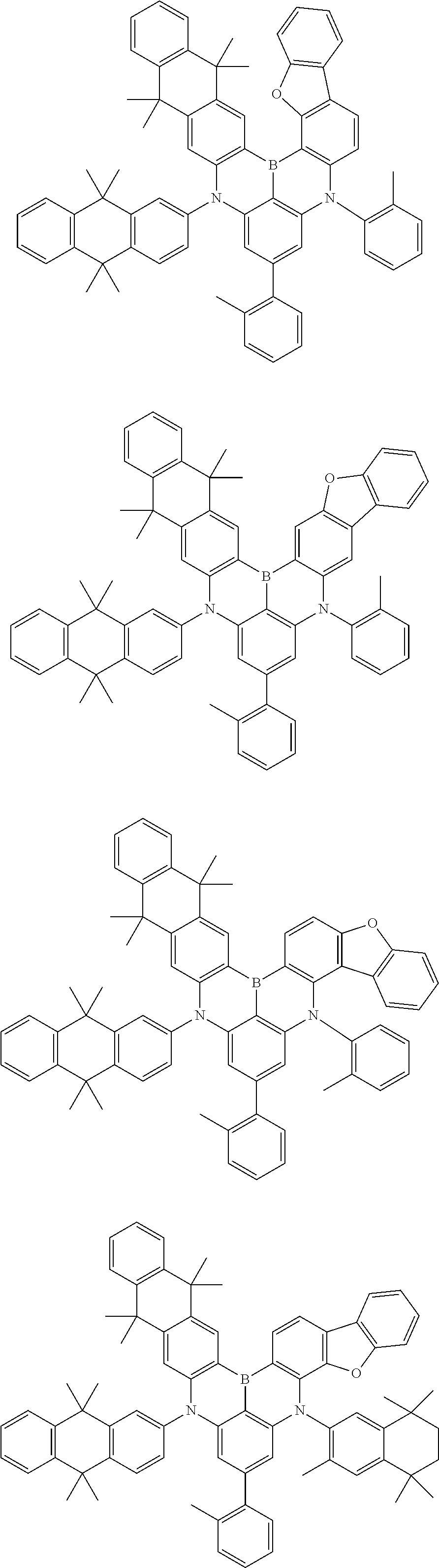

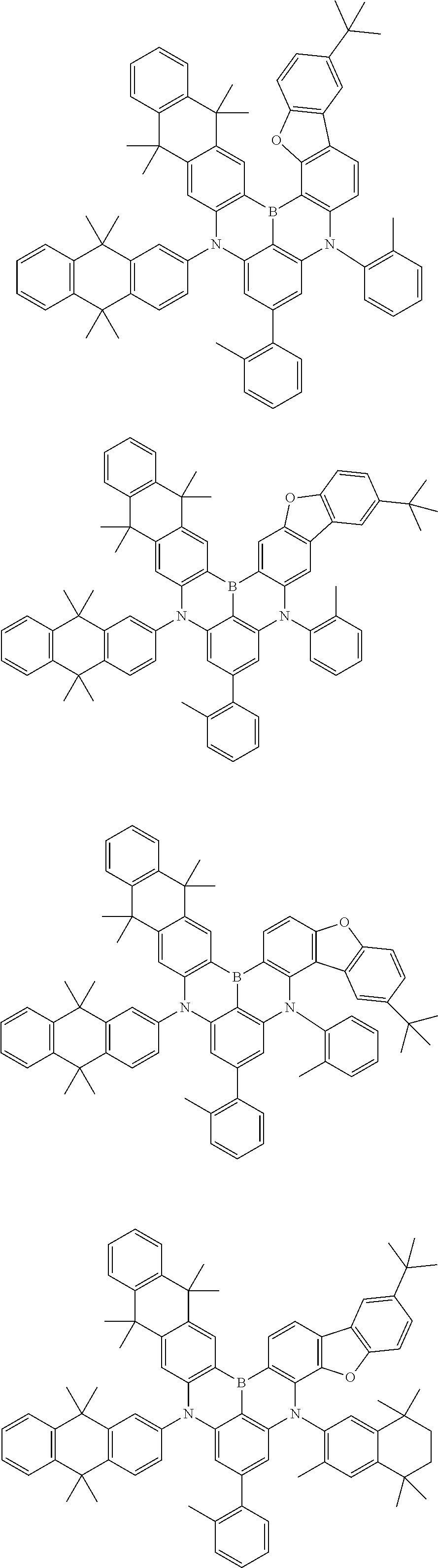

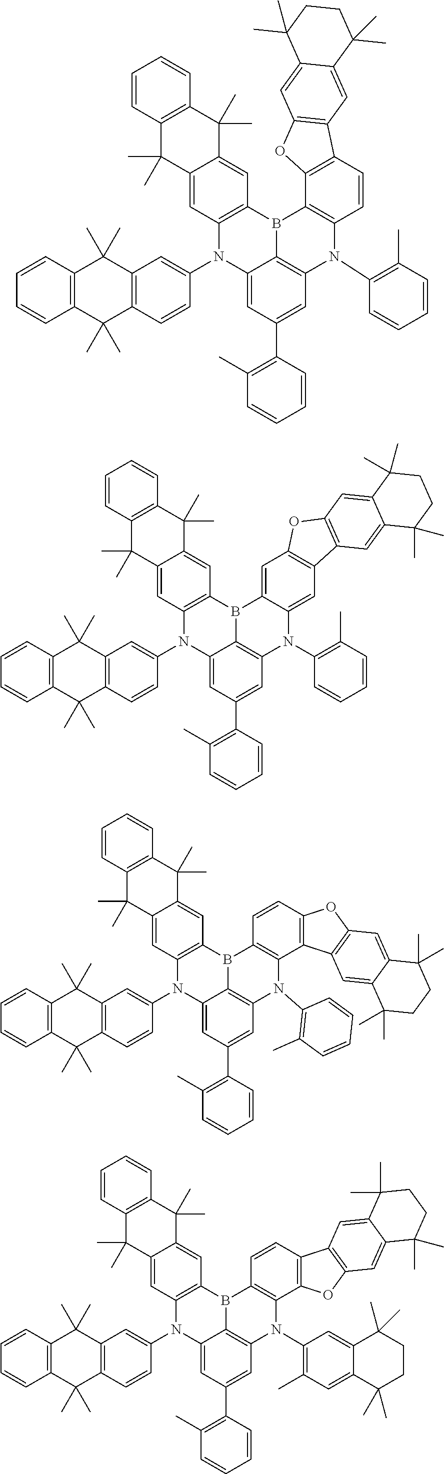

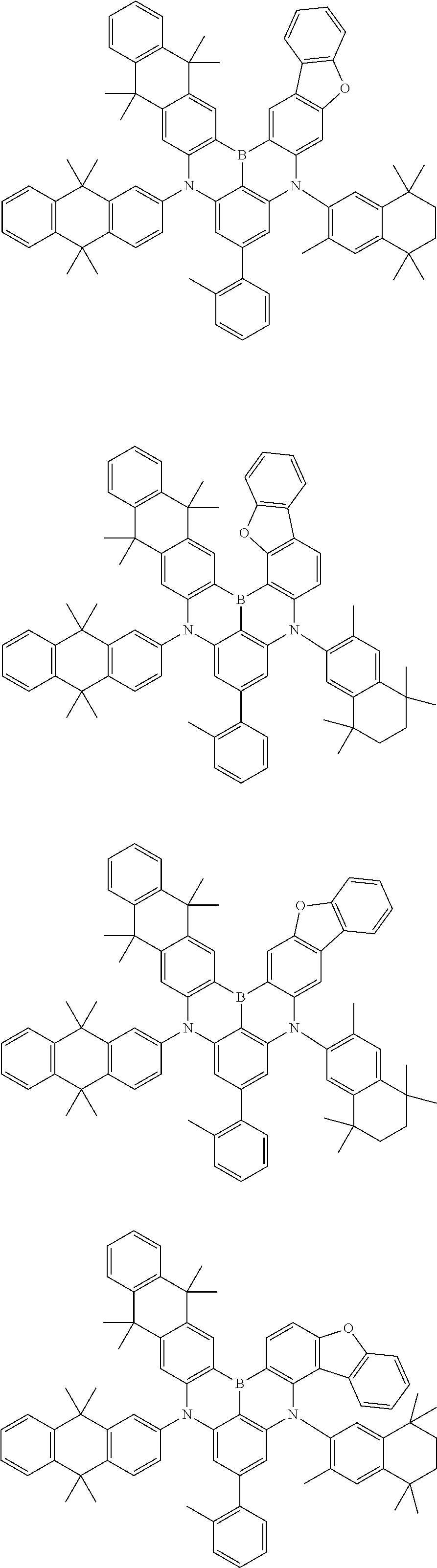

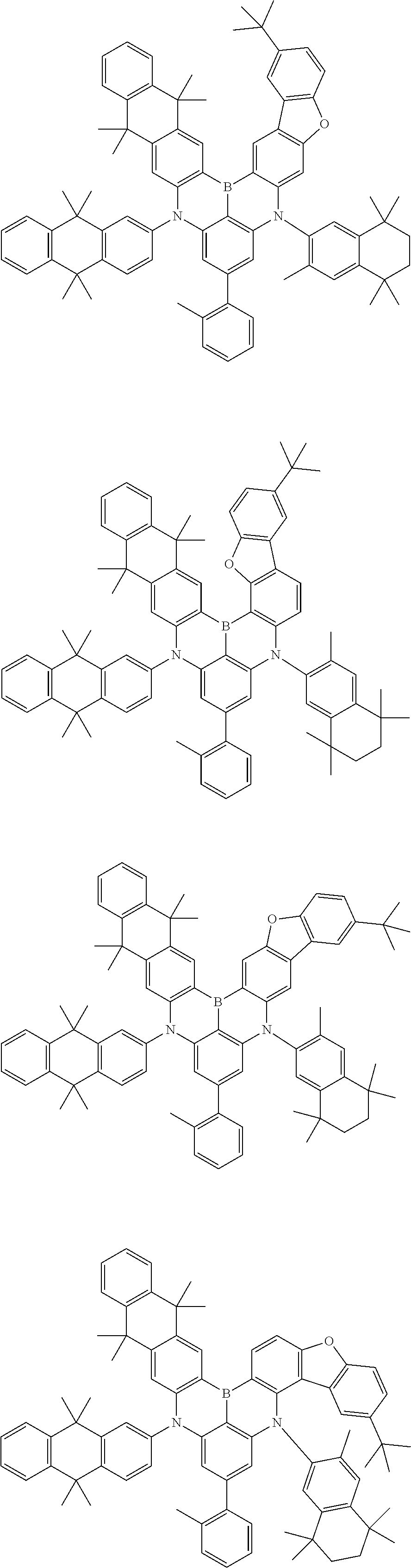

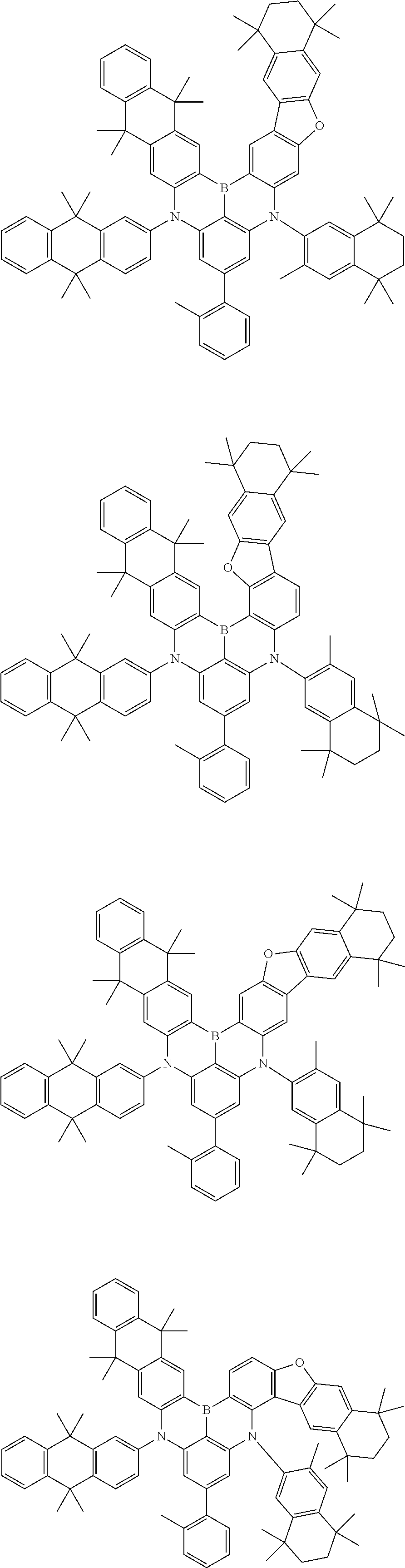

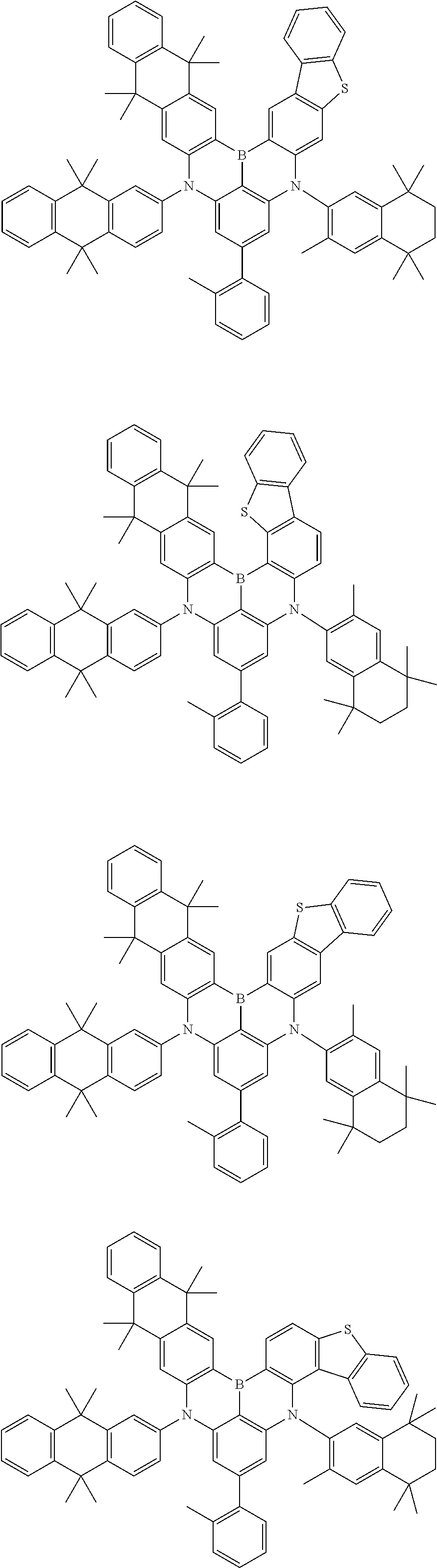

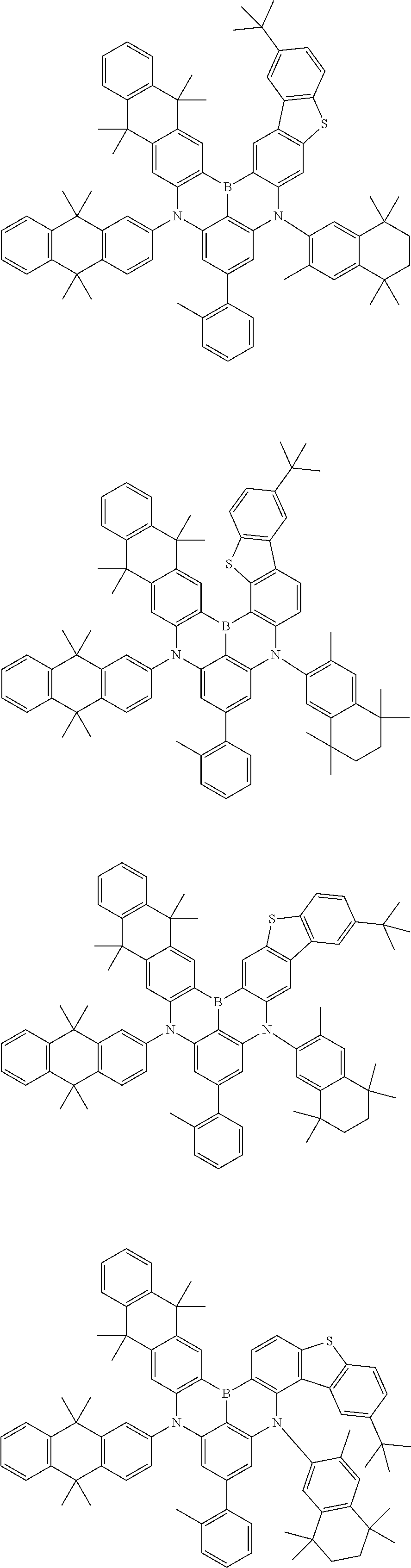

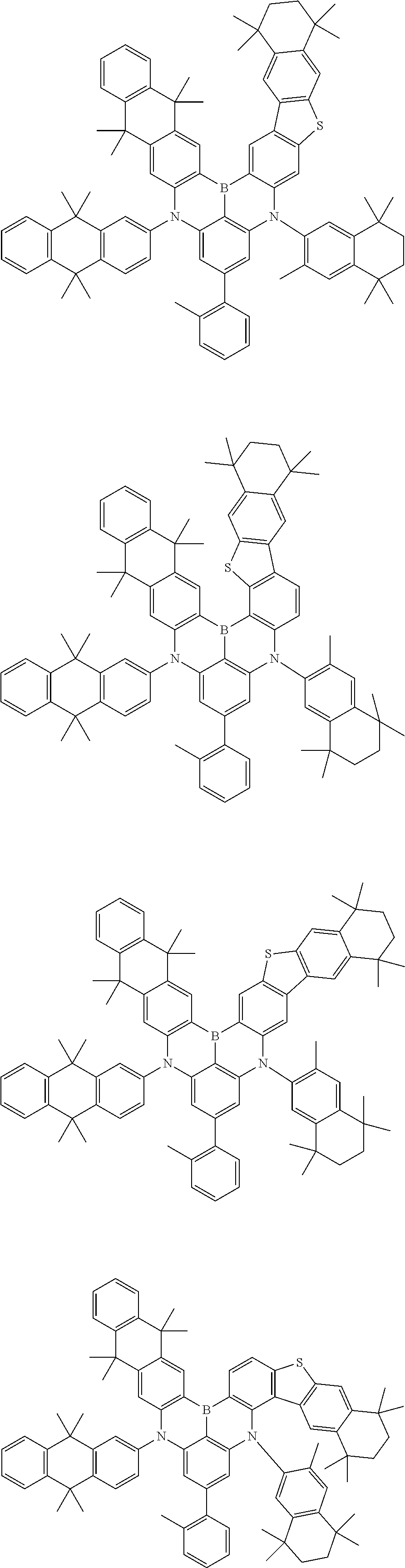

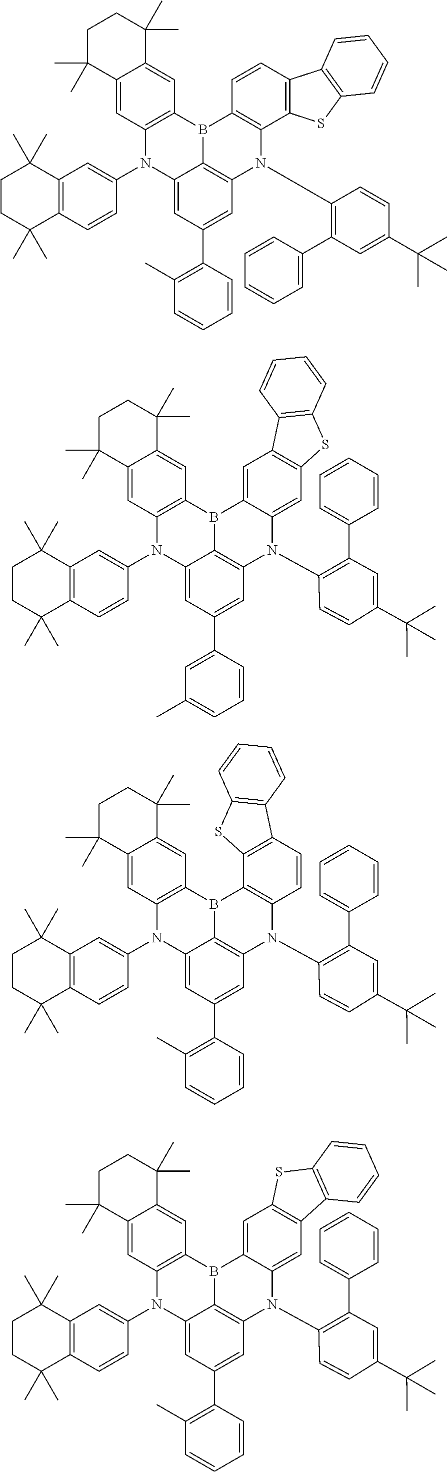

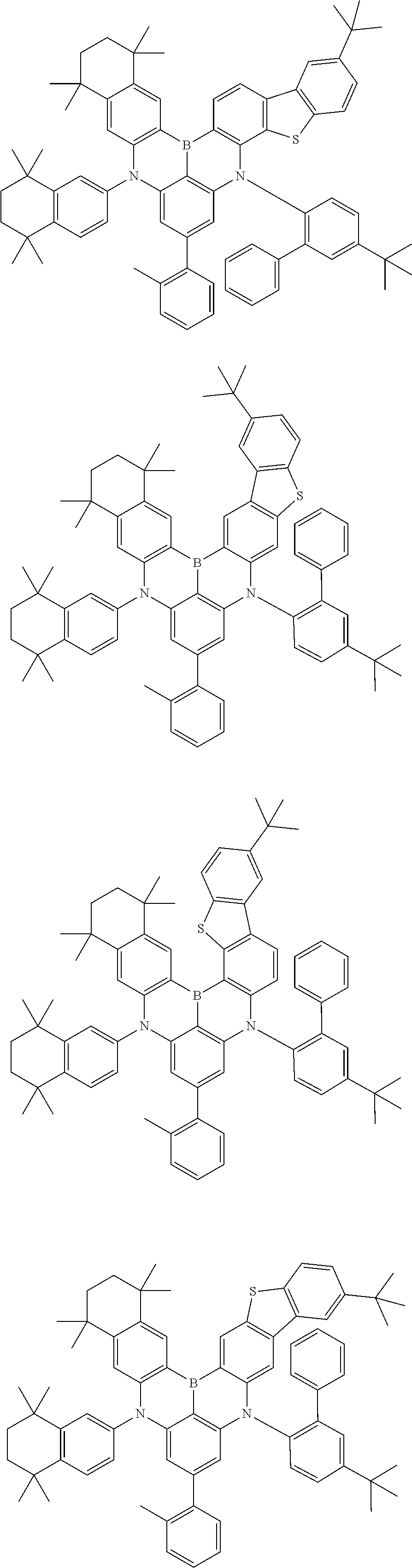

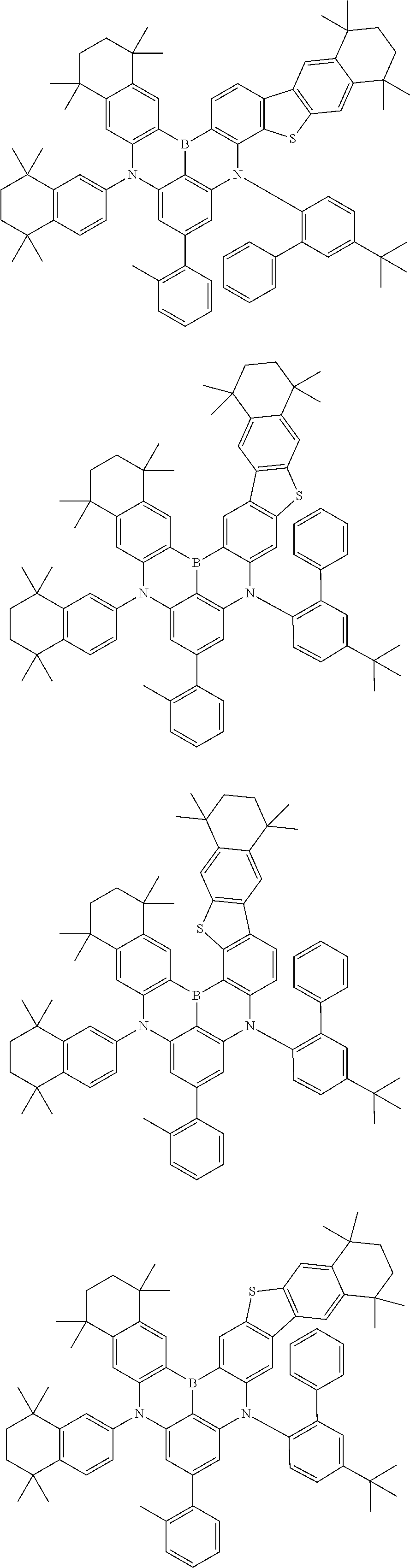

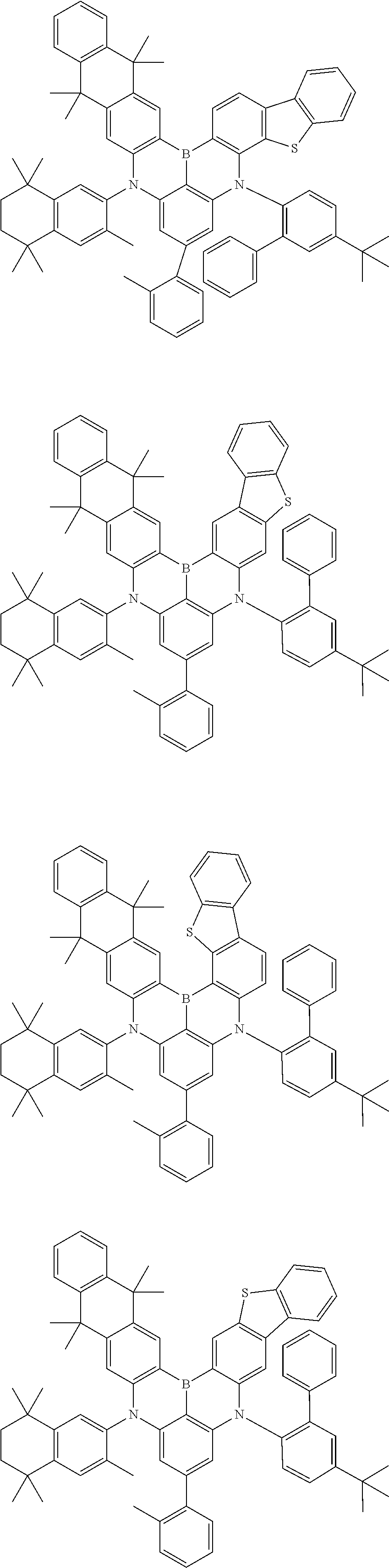

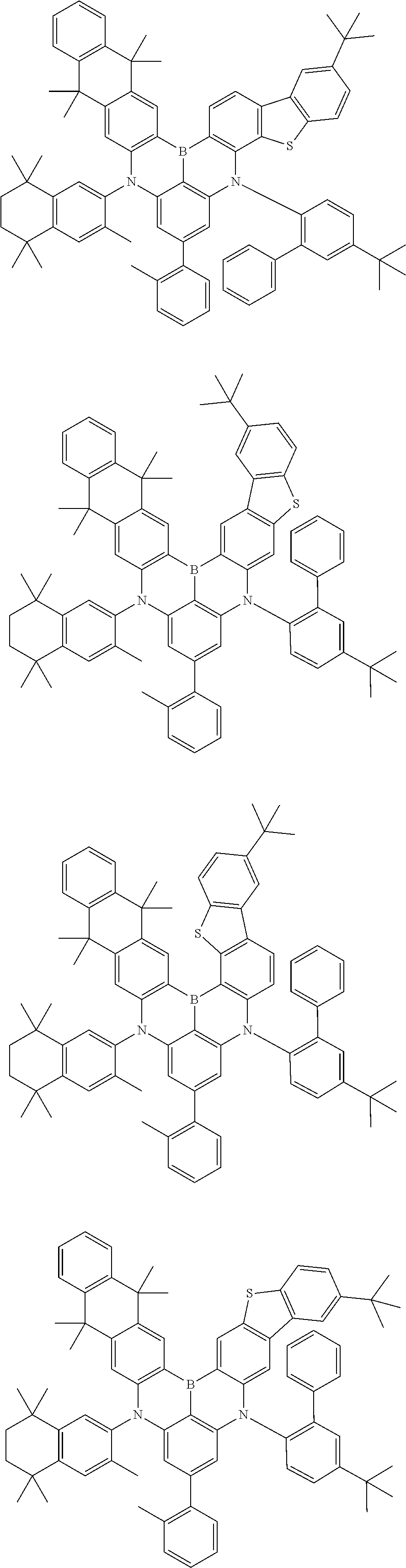

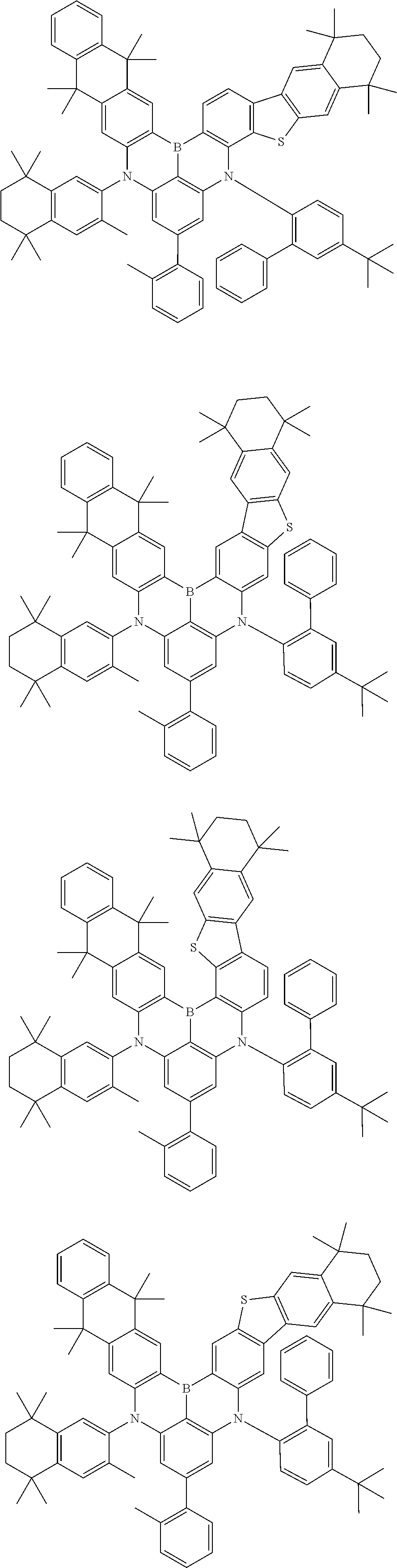

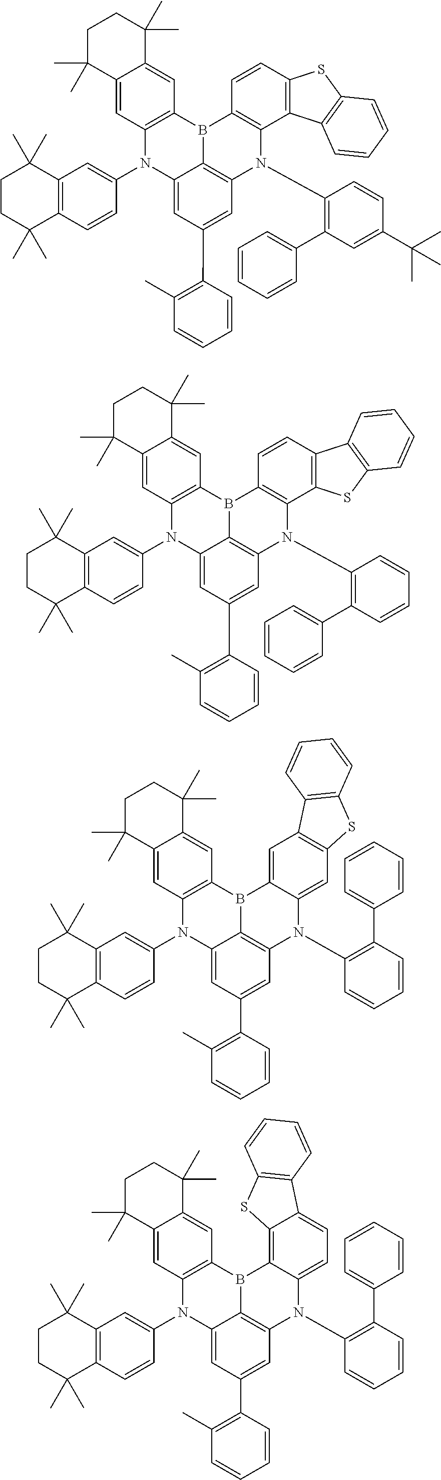

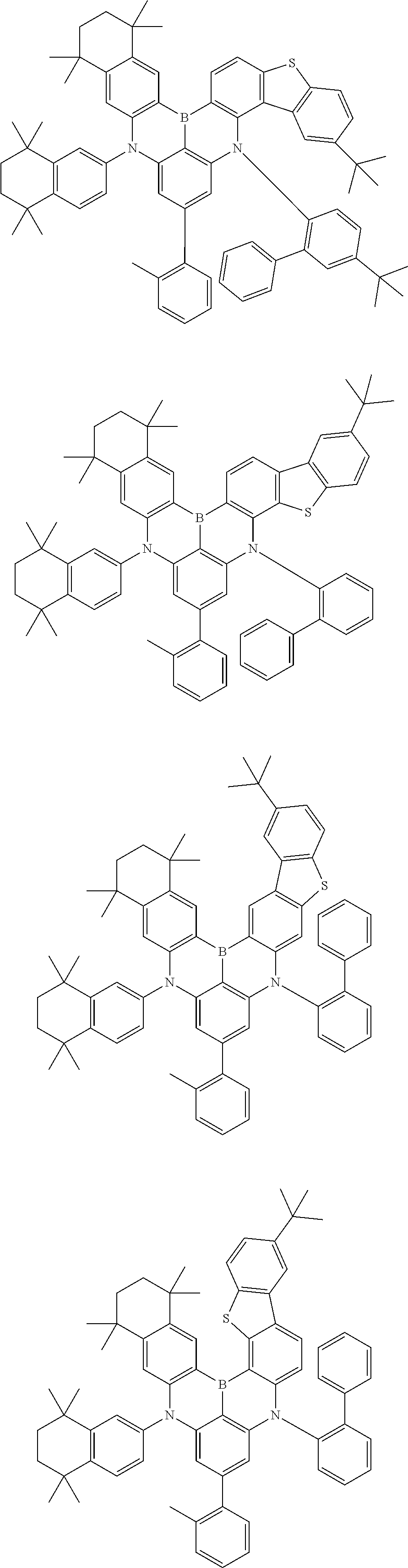

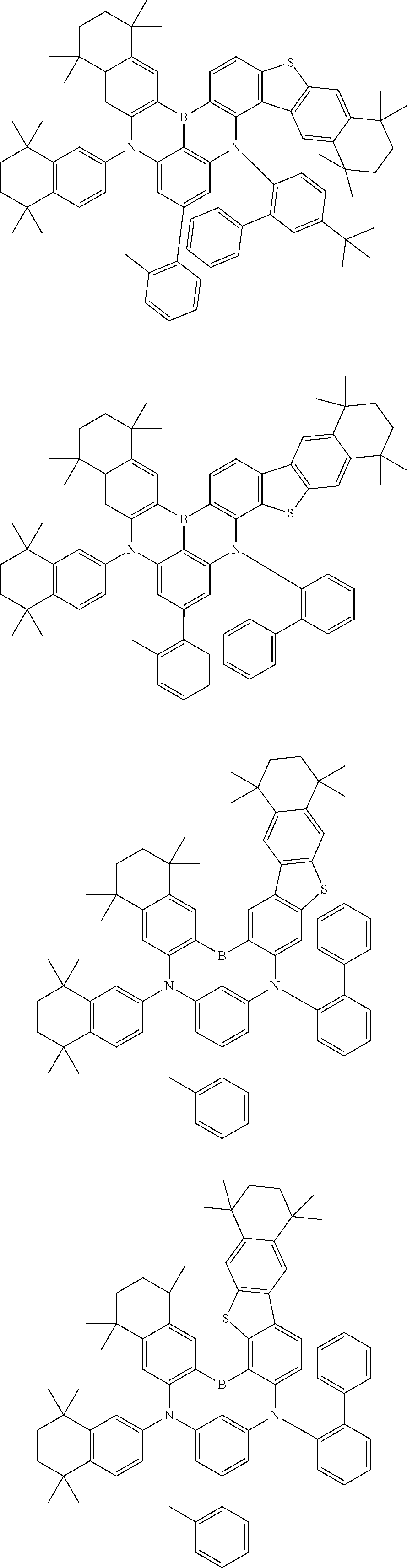

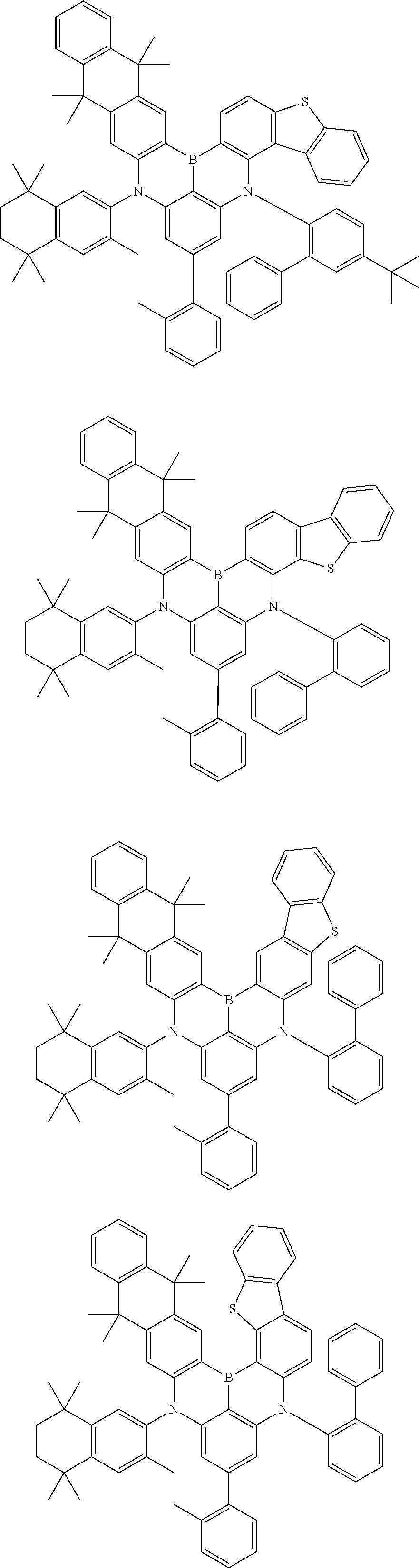

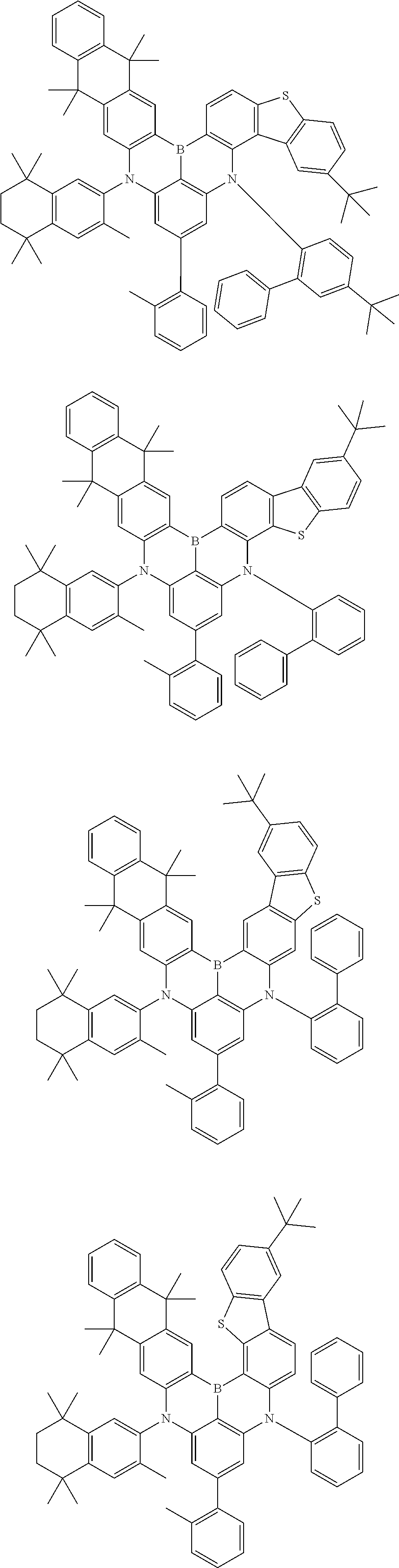

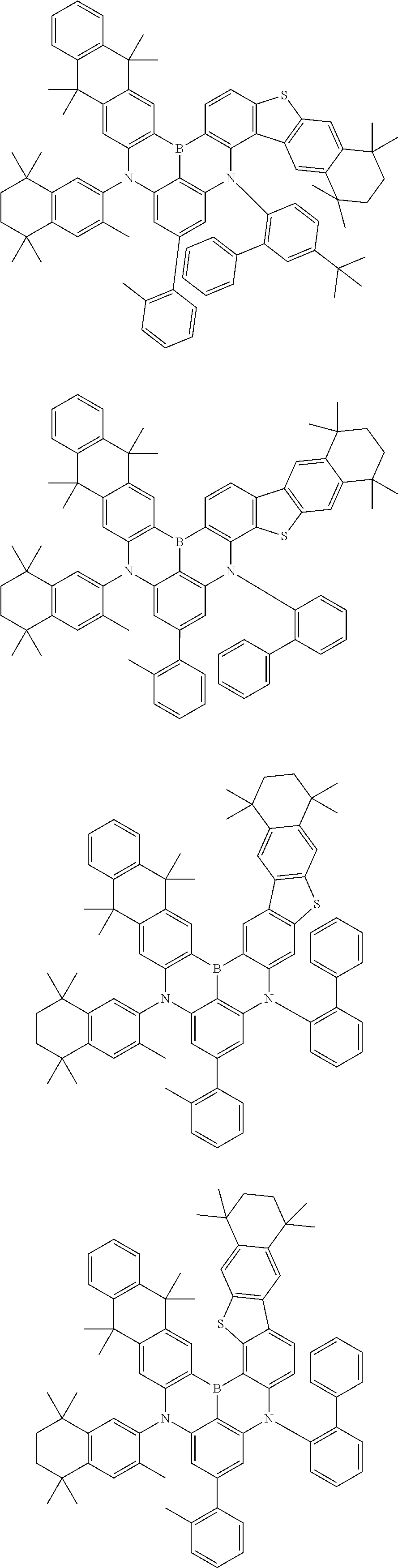

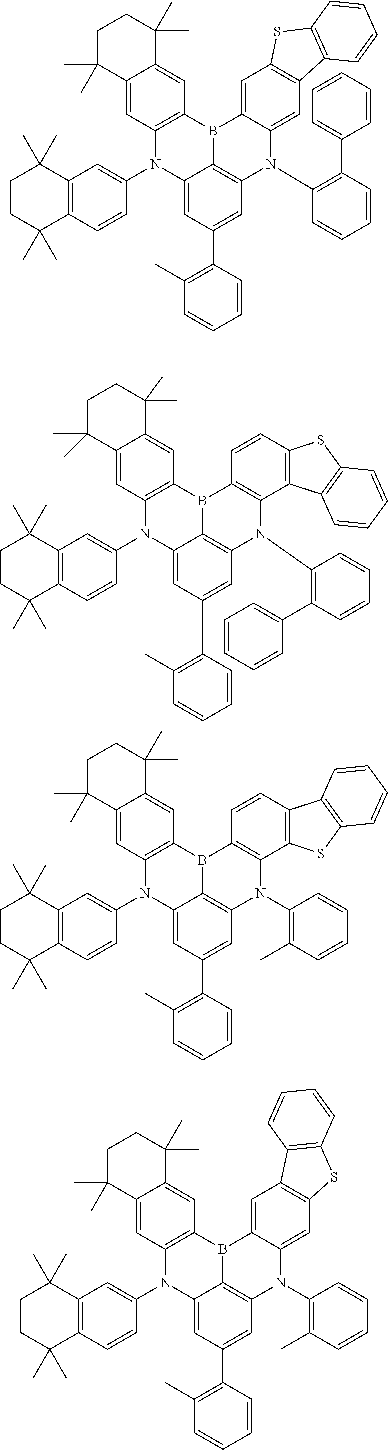

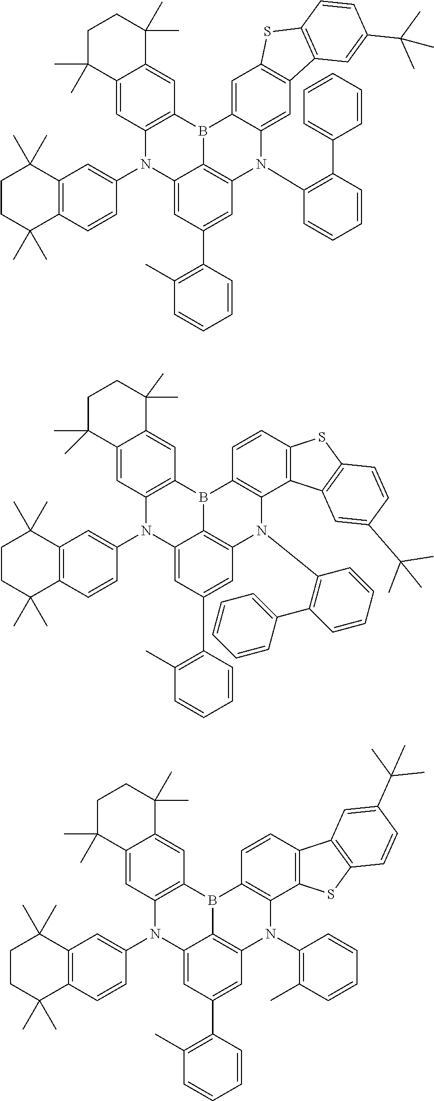 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1ccc(C(C)(C)C)cc14 ; Cc1ccccc1-c1cc2c3c(c1)N(c1ccccc1-c1ccccc1)c1c(ccc4sc5ccc(C(C)(C)C)cc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1c(ccc4c1sc1ccc(C(C)(C)C)cc14)B3c1cc3c(cc1N2c1ccc2c(c1)C(C)(C)CCC2(C)C)C(C)(C)CCC3(C)C]

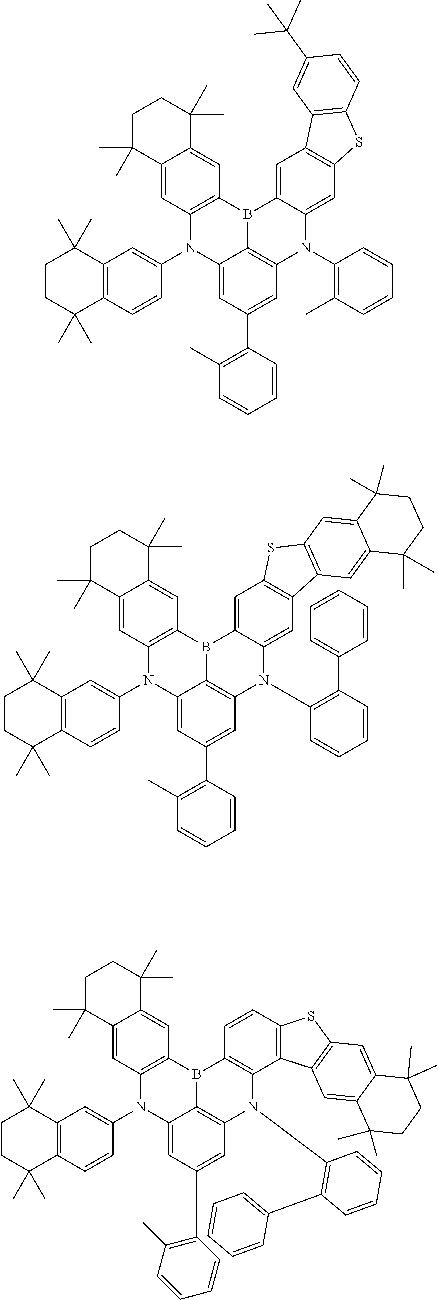 [SMILES: Cc1ccccc1-c1cc2c3c(c1)N(c1ccccc1C)c1cc4sc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1cc2c(cc14)C(C)(C)CCC2(C)C ; Cc1ccccc1-c1cc2c3c(c1)N(c1ccccc1-c1ccccc1)c1c(ccc4sc5cc6c(cc5c14)C(C)(C)CCC6(C)C)B3c1cc3c(cc1N2c1ccc2c(c1)C(C)(C)CCC2(C)C)C(C)(C)CCC3(C)C]

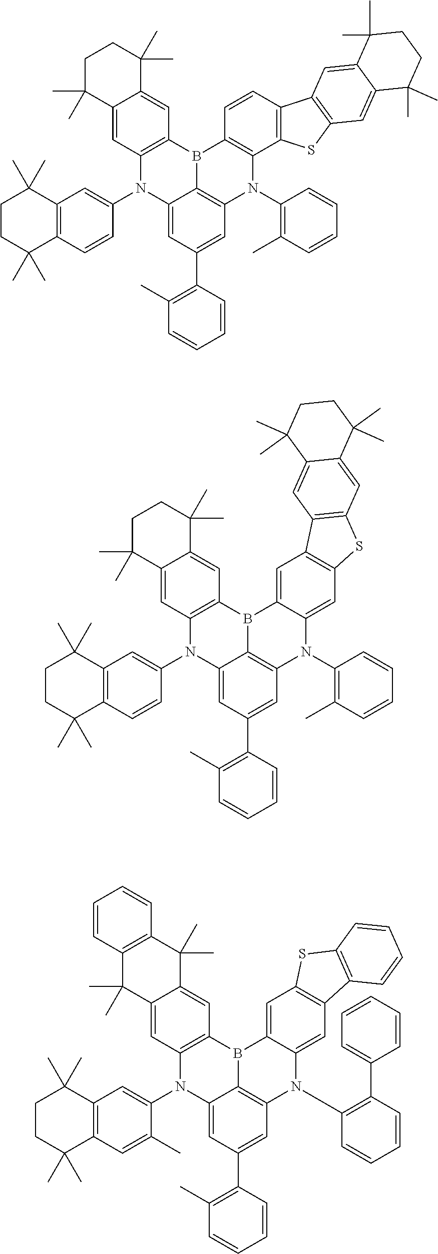 [SMILES: Cc1ccccc1-c1cc2c3c(c1)N(c1ccccc1C)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4sc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccccc14]

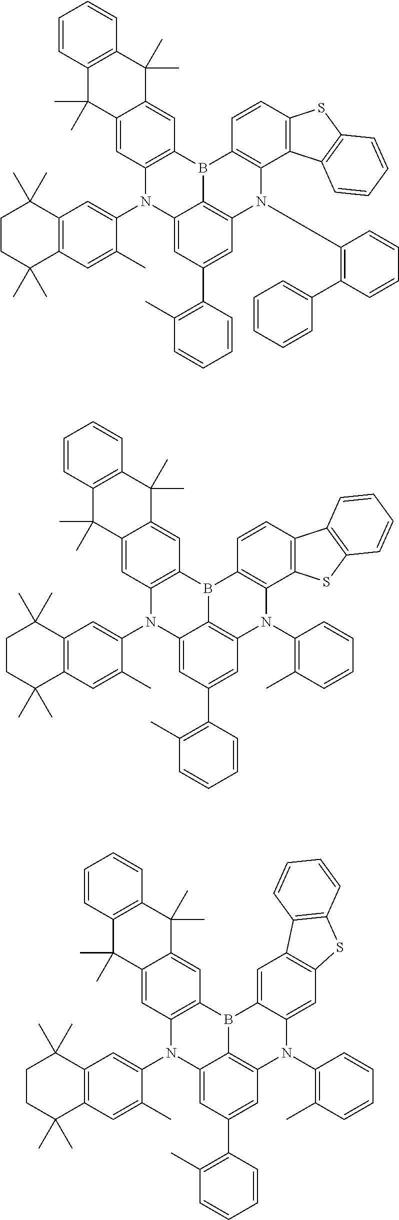 [SMILES: Cc1ccccc1-c1cc2c3c(c1)N(c1ccccc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4sc5ccccc5c4cc1B3c1cc3c(cc1N2c1cc2c(cc1C)C(C)(C)CCC2(C)C)C(C)(C)c1ccccc1C3(C)C]

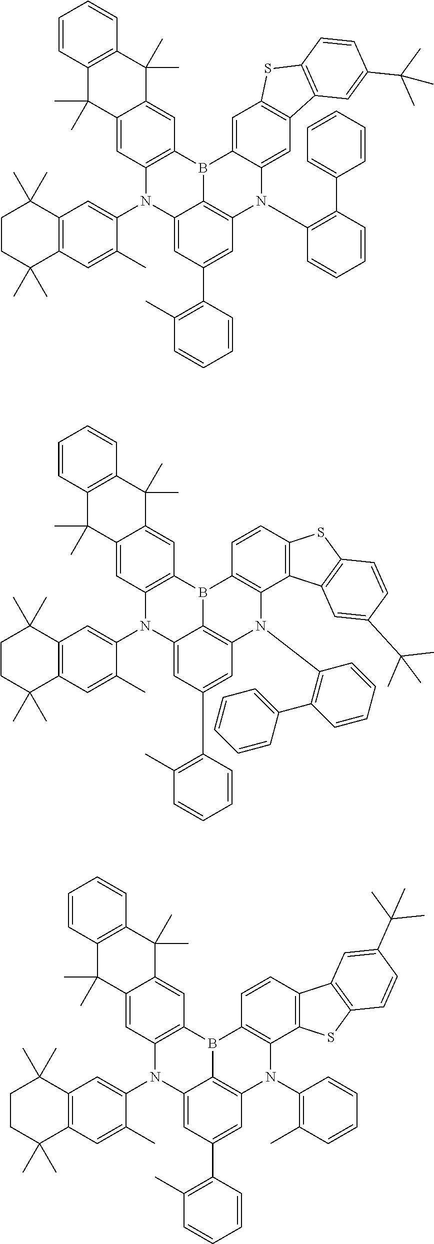 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14 ; Cc1ccccc1-c1cc2c3c(c1)N(c1ccccc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C]

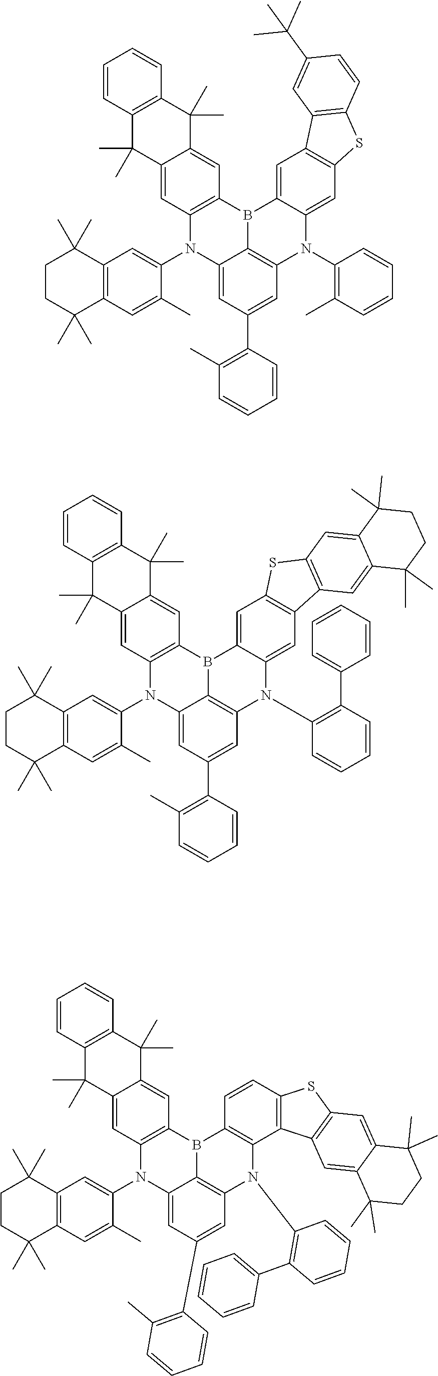

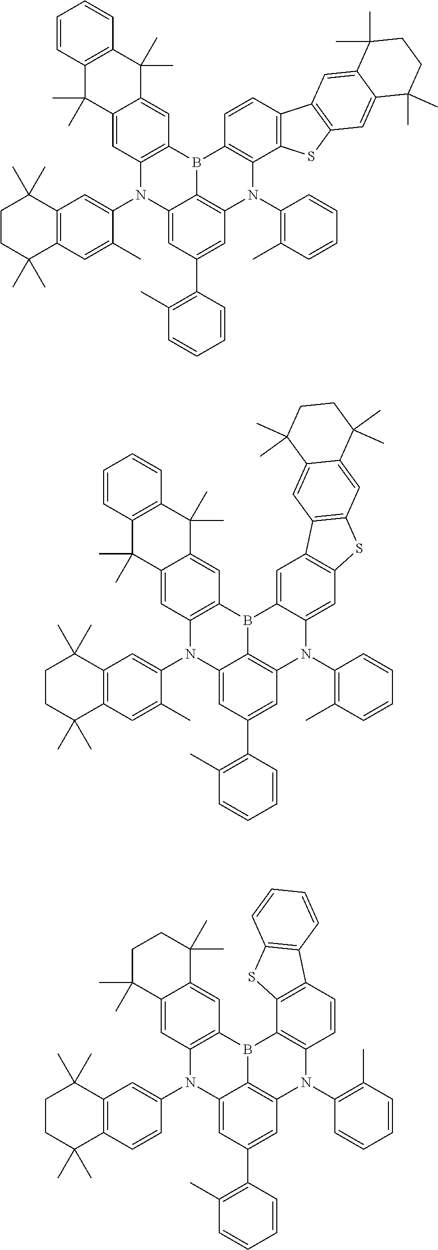 [SMILES: Cc1ccccc1-c1cc2c3c(c1)N(c1ccccc1C)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4sc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1ccccc1-c1cc2c3c(c1)N(c1ccccc1C)c1ccc4c(sc5ccccc54)c1B3c1cc3c(cc1N2c1ccc2c(c1)C(C)(C)CCC2(C)C)C(C)(C)CCC3(C)C]

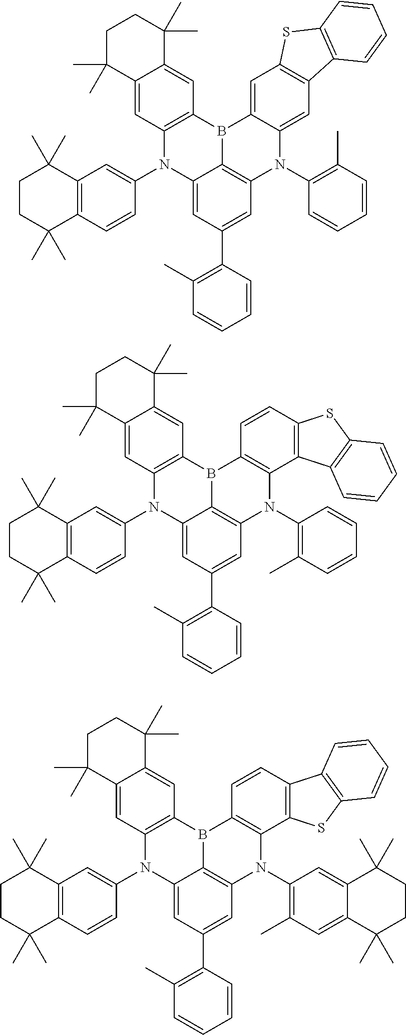

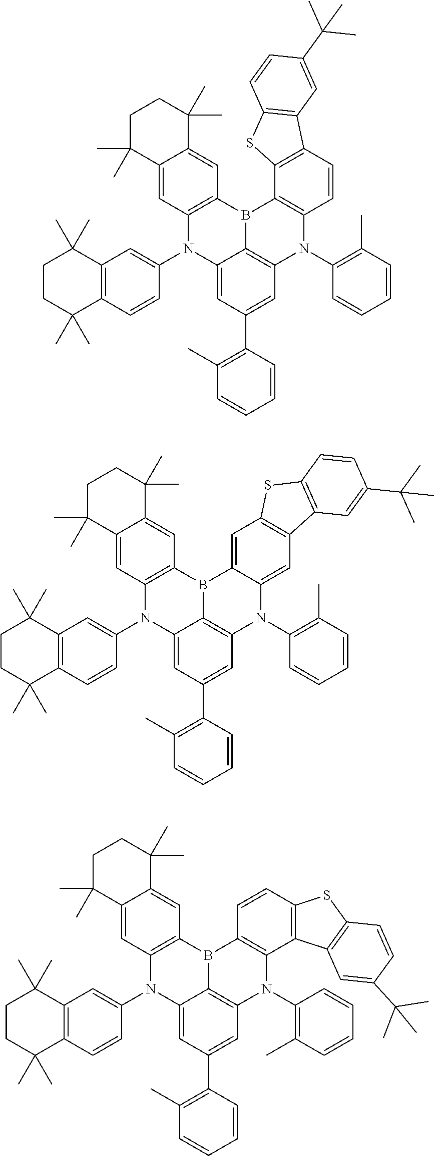 [SMILES: Cc1ccccc1-c1cc2c3c(c1)N(c1ccccc1C)c1ccc4c(sc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4c(cc1B3c1cc3c(cc1N2c1ccc2c(c1)C(C)(C)CCC2(C)C)C(C)(C)CCC3(C)C)sc1ccc(C(C)(C)C)cc14 ; Cc1ccccc1-c1cc2c3c(c1)N(c1ccccc1C)c1c(ccc4sc5ccc(C(C)(C)C)cc5c14)B3c1cc3c(cc1N2c1ccc2c(c1)C(C)(C)CCC2(C)C)C(C)(C)CCC3(C)C]

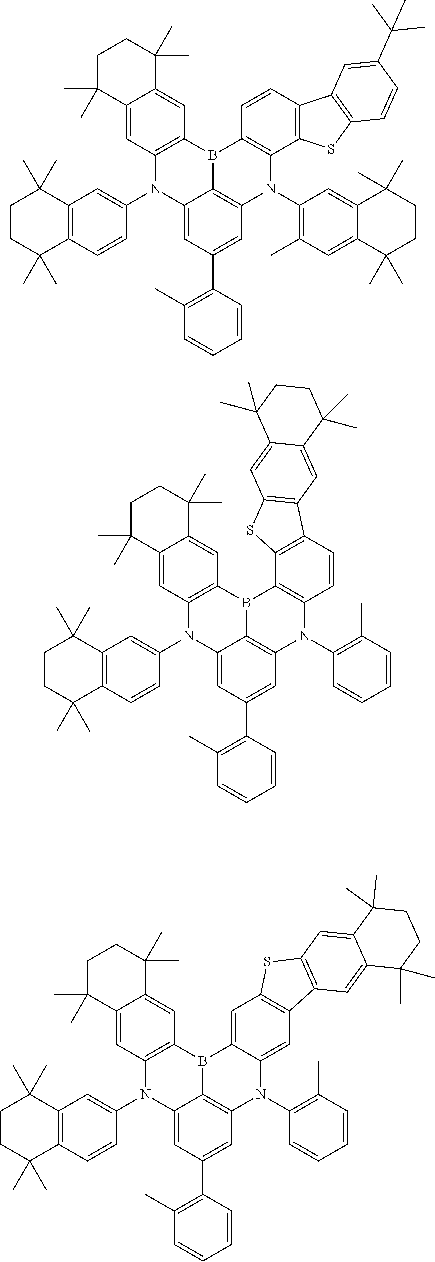

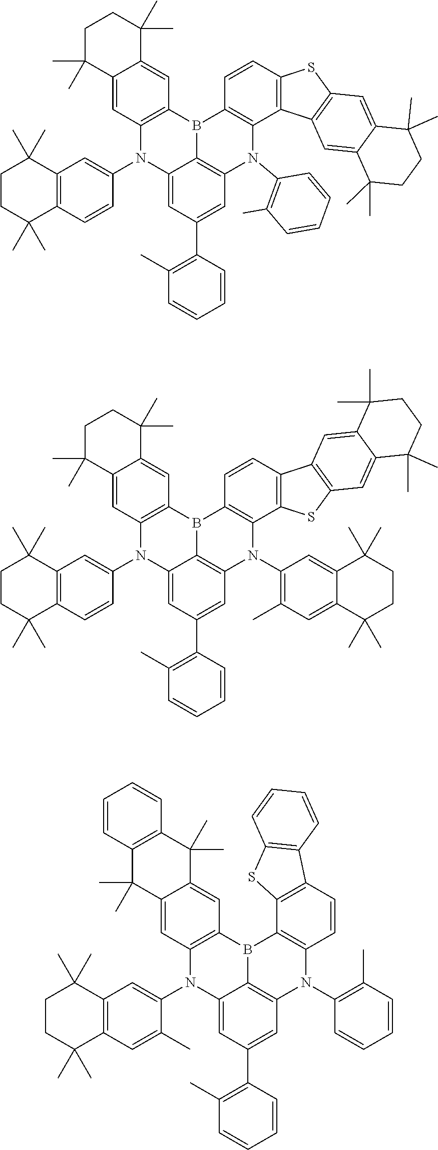 [SMILES: Cc1ccccc1-c1cc2c3c(c1)N(c1ccccc1C)c1c(ccc4sc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1ccc4c(sc5ccccc54)c1B3c1cc3c(cc1N2c1cc2c(cc1C)C(C)(C)CCC2(C)C)C(C)(C)c1ccccc1C3(C)C]

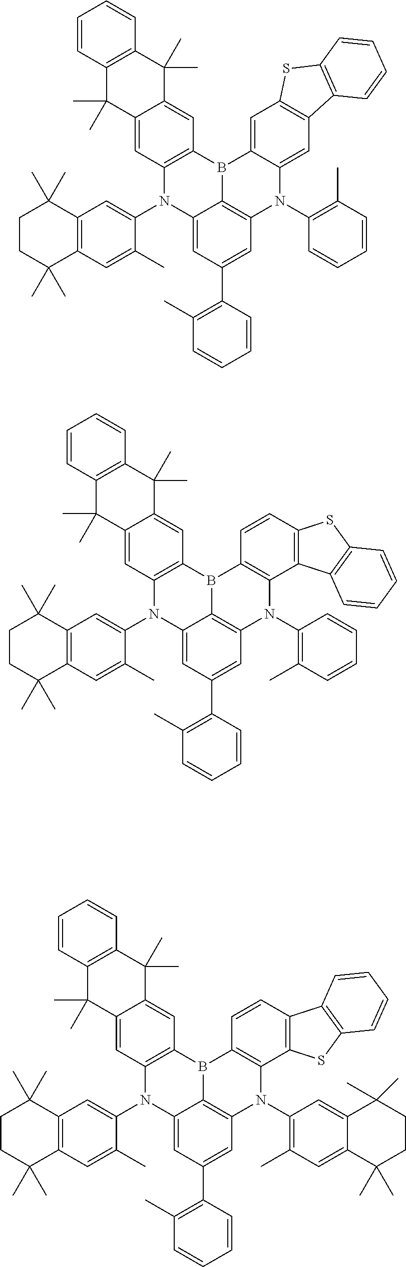 [SMILES: Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)sc1ccccc14 ; Cc1ccccc1-c1cc2c3c(c1)N(c1ccccc1C)c1c(ccc4sc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1sc1ccccc14)B3c1cc3c(cc1N2c1cc2c(cc1C)C(C)(C)CCC2(C)C)C(C)(C)c1ccccc1C3(C)C]

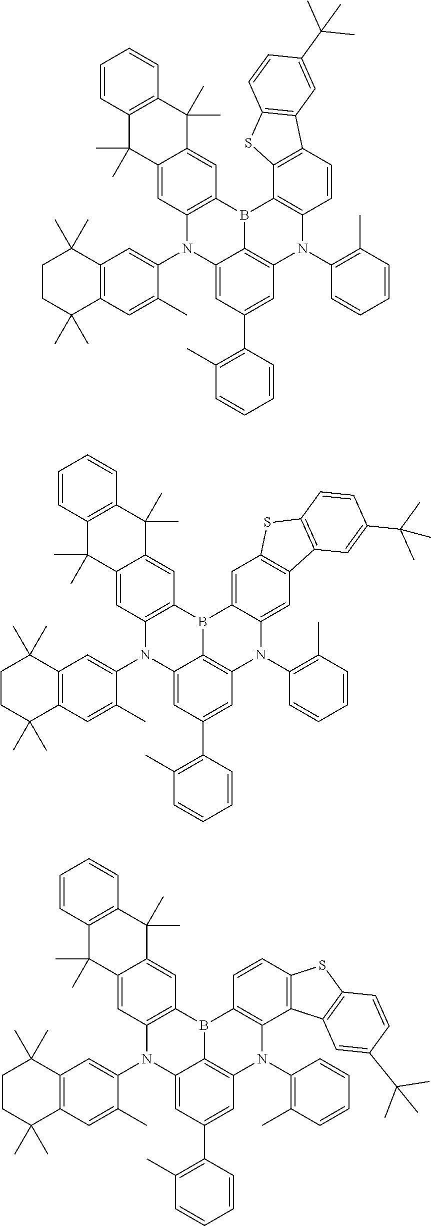 [SMILES: Cc1ccccc1-c1cc2c3c(c1)N(c1ccccc1C)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14 ; Cc1ccccc1-c1cc2c3c(c1)N(c1ccccc1C)c1c(ccc4sc5ccc(C(C)(C)C)cc5c14)B3c1cc3c(cc1N2c1cc2c(cc1C)C(C)(C)CCC2(C)C)C(C)(C)c1ccccc1C3(C)C]

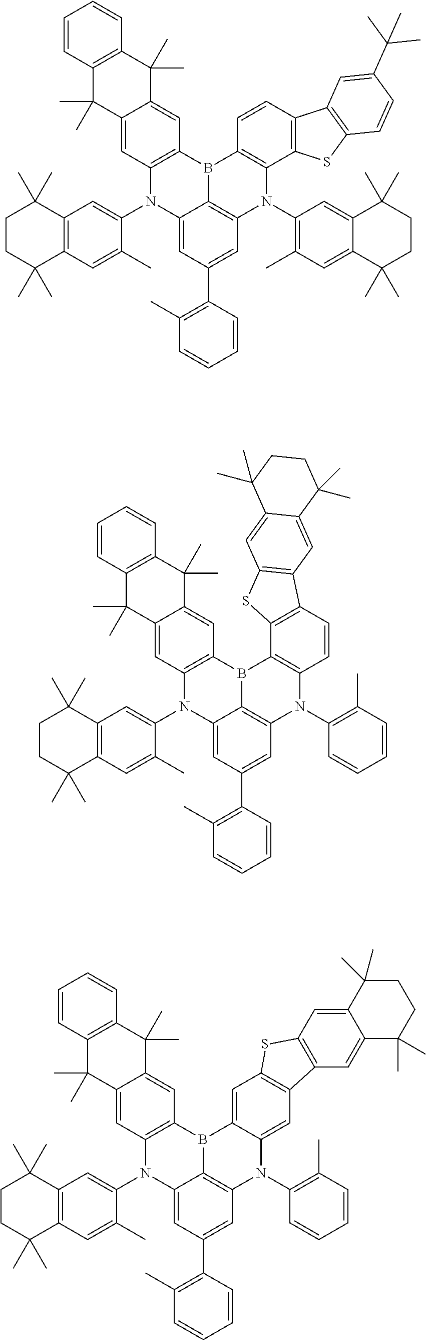 [SMILES: Cc1ccccc1-c1cc2c3c(c1)N(c1cc4c(cc1C)C(C)(C)CCC4(C)C)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1ccc4c(sc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)sc1cc2c(cc14)C(C)(C)CCC2(C)C]

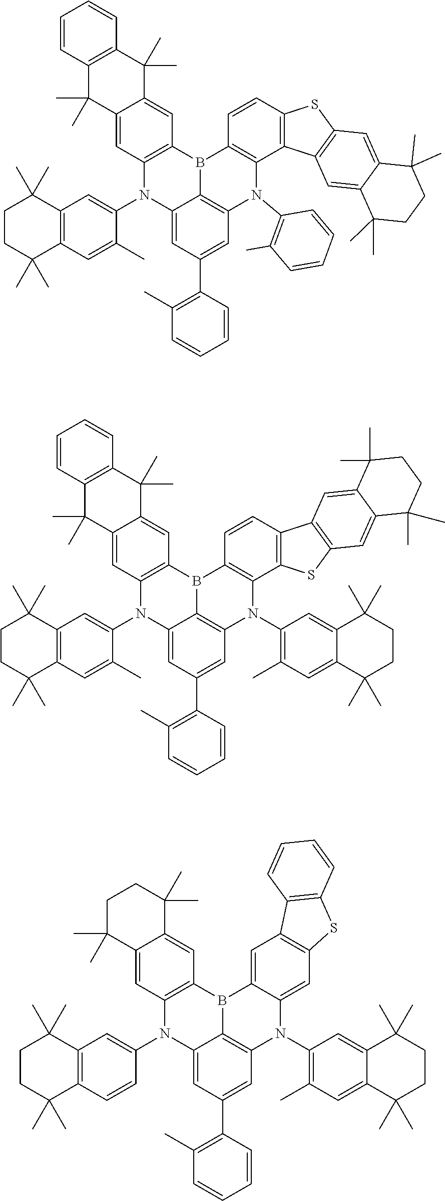 [SMILES: Cc1ccccc1-c1cc2c3c(c1)N(c1ccccc1C)c1c(ccc4sc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1cc4sc5ccccc5c4cc1B3c1cc3c(cc1N2c1ccc2c(c1)C(C)(C)CCC2(C)C)C(C)(C)CCC3(C)C]

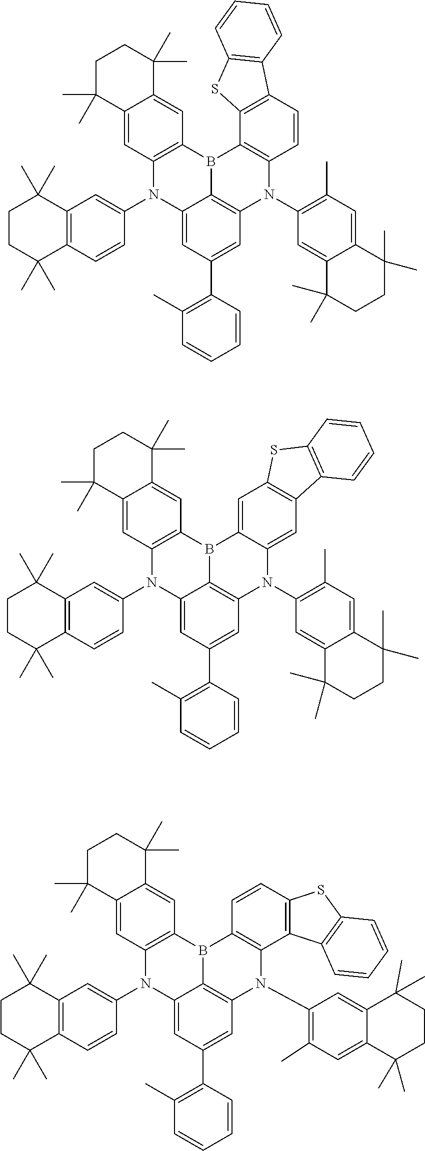 [SMILES: Cc1ccccc1-c1cc2c3c(c1)N(c1cc4c(cc1C)C(C)(C)CCC4(C)C)c1ccc4c(sc5ccccc54)c1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1ccccc14 ; Cc1ccccc1-c1cc2c3c(c1)N(c1cc4c(cc1C)C(C)(C)CCC4(C)C)c1c(ccc4sc5ccccc5c14)B3c1cc3c(cc1N2c1ccc2c(c1)C(C)(C)CCC2(C)C)C(C)(C)CCC3(C)C]

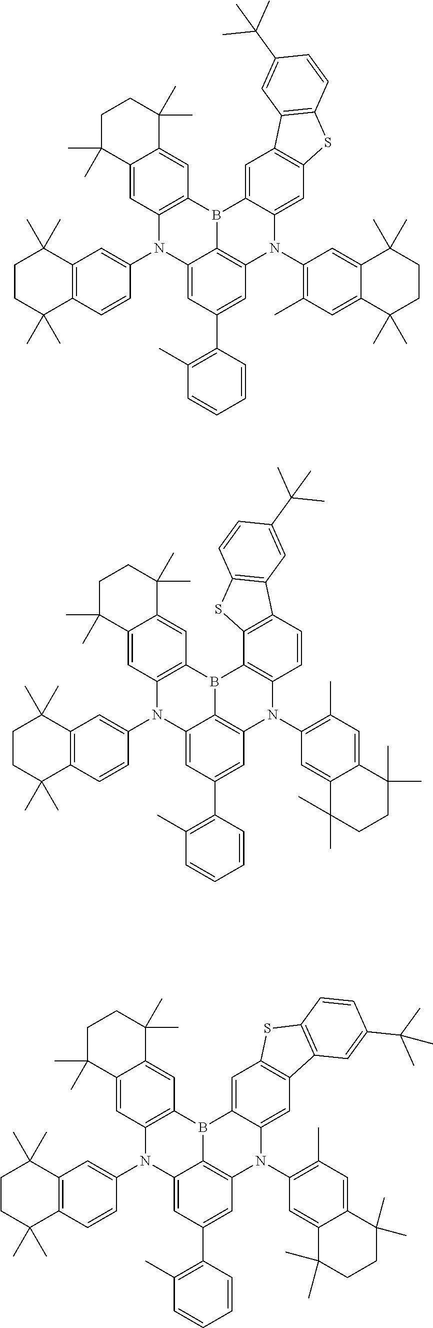 [SMILES: Cc1ccccc1-c1cc2c3c(c1)N(c1cc4c(cc1C)C(C)(C)CCC4(C)C)c1cc4sc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1ccc4c(sc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1ccc(C(C)(C)C)cc14]

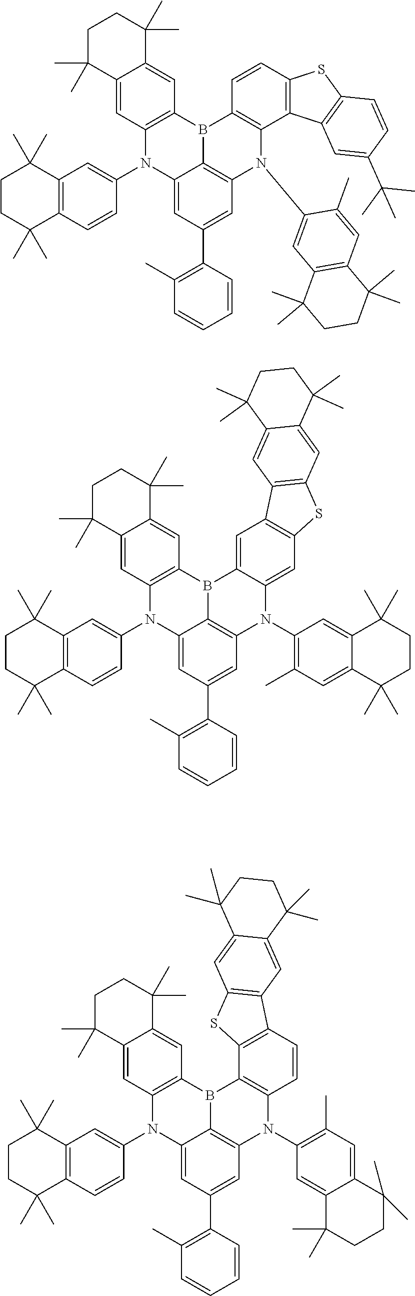

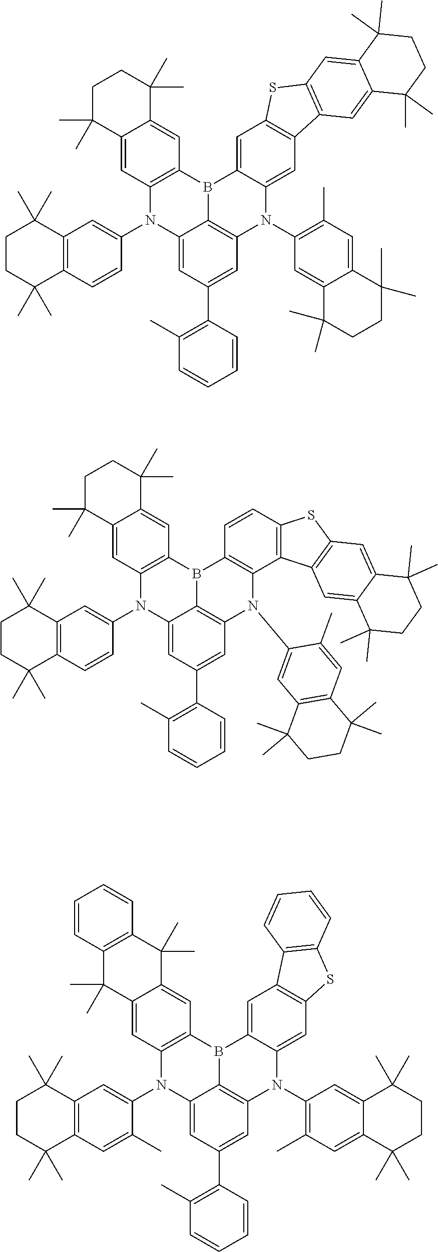 [SMILES: Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1cc2c(cc14)C(C)(C)CCC2(C)C ; Cc1ccccc1-c1cc2c3c(c1)N(c1cc4c(cc1C)C(C)(C)CCC4(C)C)c1c(ccc4sc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4sc5ccccc5c4cc1B3c1cc3c(cc1N2c1cc2c(cc1C)C(C)(C)CCC2(C)C)C(C)(C)c1ccccc1C3(C)C]

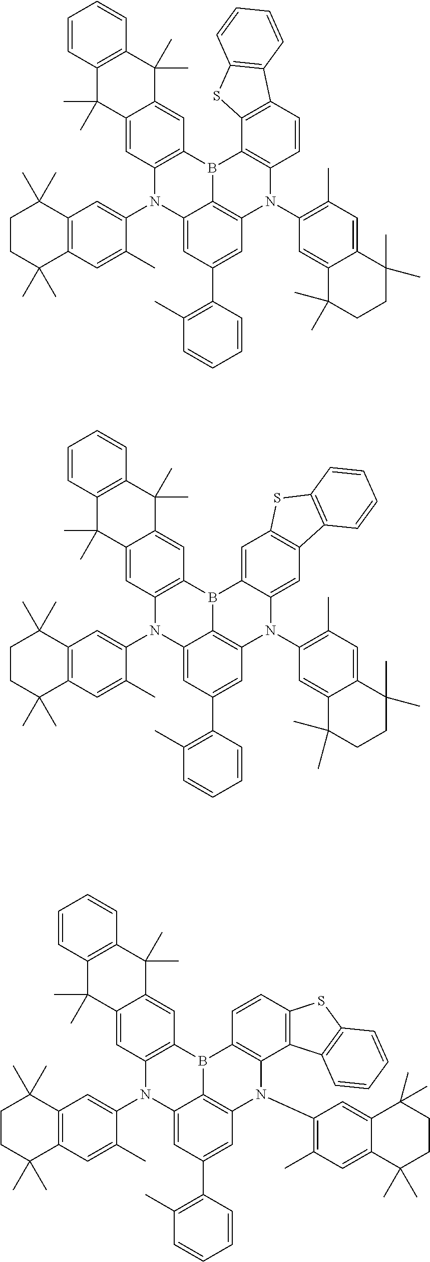 [SMILES: Cc1ccccc1-c1cc2c3c(c1)N(c1cc4c(cc1C)C(C)(C)CCC4(C)C)c1ccc4c(sc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)sc1ccccc14 ; Cc1ccccc1-c1cc2c3c(c1)N(c1cc4c(cc1C)C(C)(C)CCC4(C)C)c1c(ccc4sc5ccccc5c14)B3c1cc3c(cc1N2c1cc2c(cc1C)C(C)(C)CCC2(C)C)C(C)(C)c1ccccc1C3(C)C]

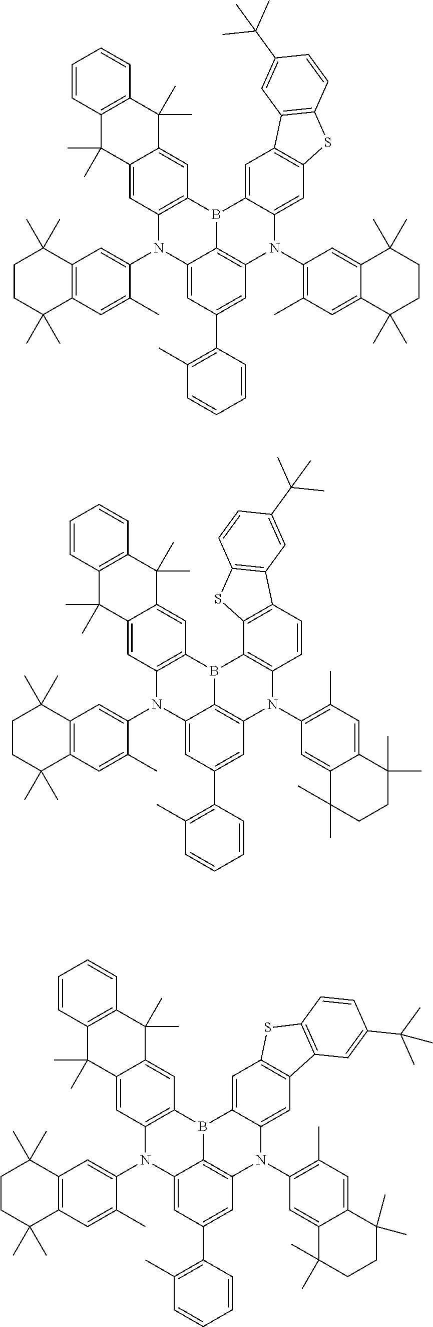 [SMILES: Cc1ccccc1-c1cc2c3c(c1)N(c1cc4c(cc1C)C(C)(C)CCC4(C)C)c1cc4sc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14]

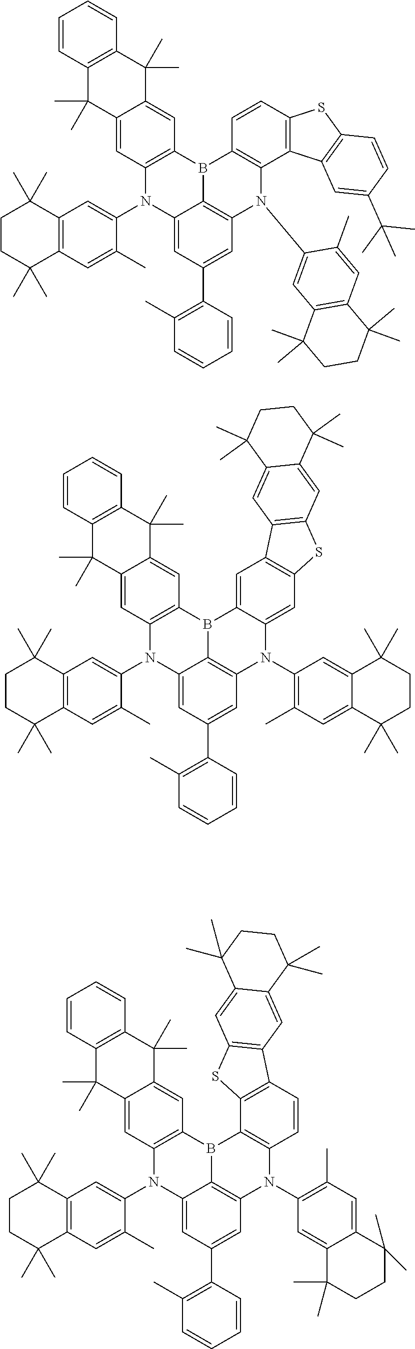

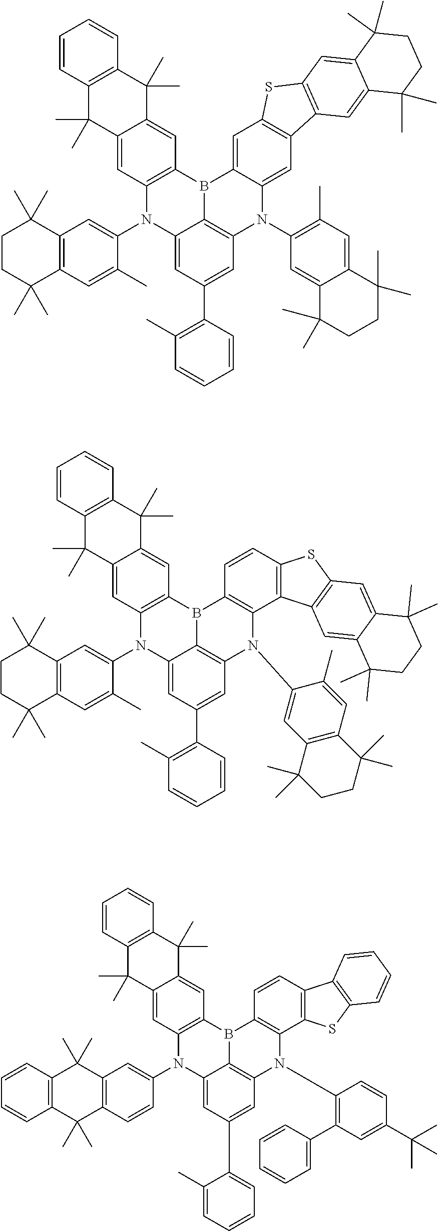 [SMILES: Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)sc1cc2c(cc14)C(C)(C)CCC2(C)C ; Cc1ccccc1-c1cc2c3c(c1)N(c1cc4c(cc1C)C(C)(C)CCC4(C)C)c1c(ccc4sc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1c(ccc4c1sc1ccccc14)B3c1cc3c(cc1N2c1ccc2c(c1)C(C)(C)c1ccccc1C2(C)C)C(C)(C)c1ccccc1C3(C)C]

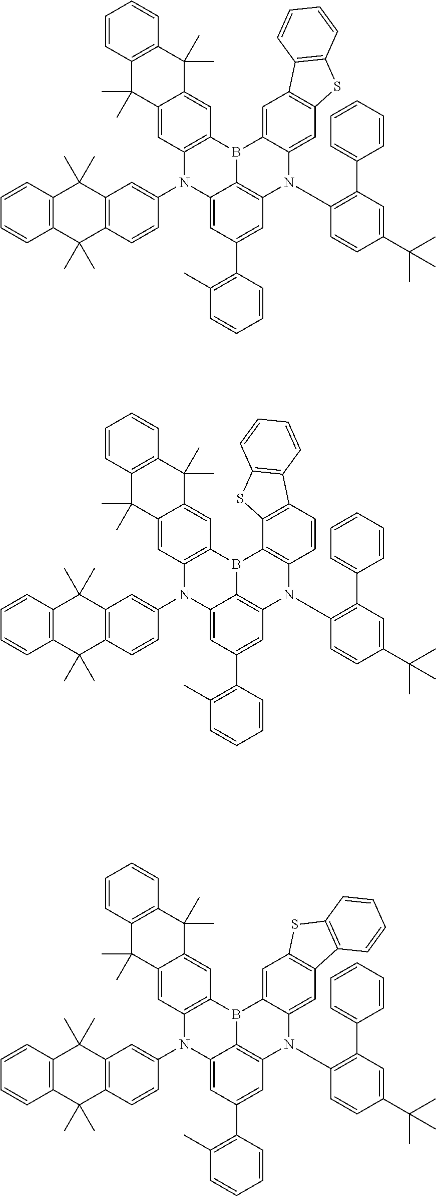 [SMILES: Cc1ccccc1-c1cc2c3c(c1)N(c1ccc(C(C)(C)C)cc1-c1ccccc1)c1cc4sc5ccccc5c4cc1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1ccc4c(sc5ccccc54)c1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1ccccc14]

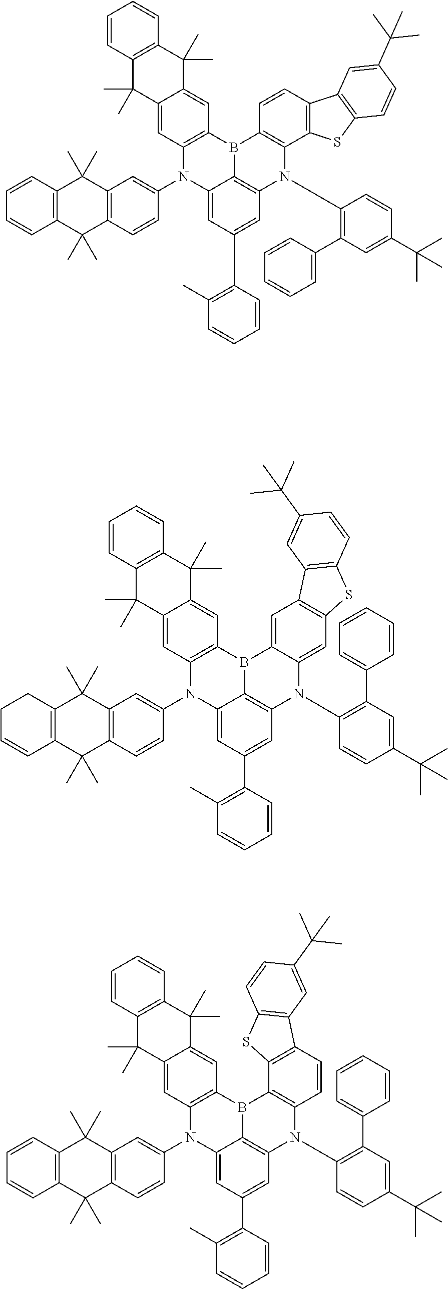 [SMILES: Cc1ccccc1-c1cc2c3c(c1)N(c1ccc(C(C)(C)C)cc1-c1ccccc1)c1c(ccc4c1sc1ccc(C(C)(C)C)cc14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1cc4sc5ccc(C(C)(C)C)cc5c4cc1B3c1cc3c(cc1N2c1ccc2c(c1)C(C)(C)C1=C(C=CCC1)C2(C)C)C(C)(C)c1ccccc1C3(C)C ; Cc1ccccc1-c1cc2c3c(c1)N(c1ccc(C(C)(C)C)cc1-c1ccccc1)c1ccc4c(sc5ccc(C(C)(C)C)cc54)c1B3c1cc3c(cc1N2c1ccc2c(c1)C(C)(C)c1ccccc1C2(C)C)C(C)(C)c1ccccc1C3(C)C]

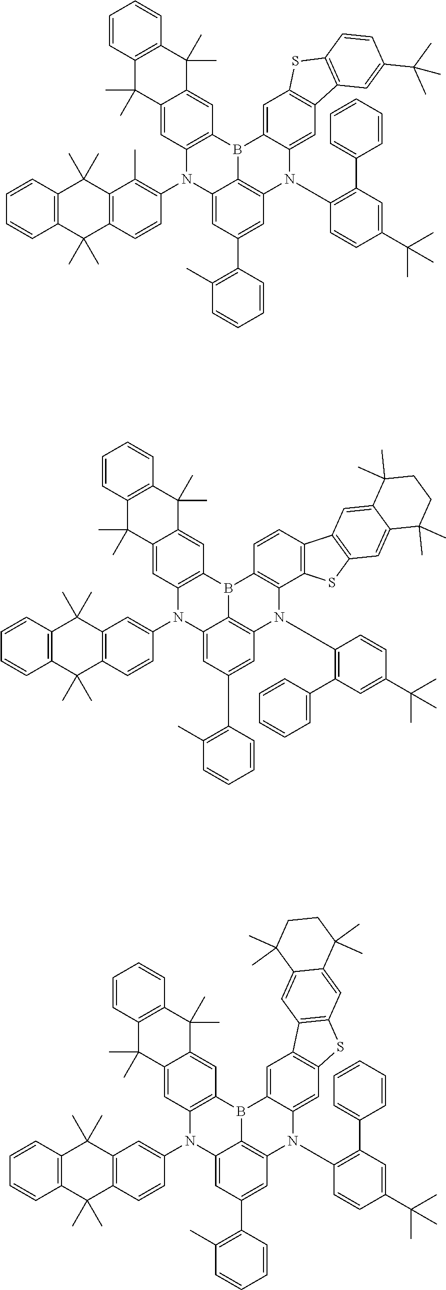 [SMILES: Cc1ccccc1-c1cc2c3c(c1)N(c1ccc4c(c1C)C(C)(C)c1ccccc1C4(C)C)c1cc4c(cc1B3c1cc3sc5ccc(C(C)(C)C)cc5c3cc1N2c1ccc(C(C)(C)C)cc1-c1ccccc1)C(C)(C)c1ccccc1C4(C)C ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1cc4sc5cc6c(cc5c4cc1B3c1cc3c(cc1N2c1ccc2c(c1)C(C)(C)c1ccccc1C2(C)C)C(C)(C)c1ccccc1C3(C)C)C(C)(C)CCC6(C)C]

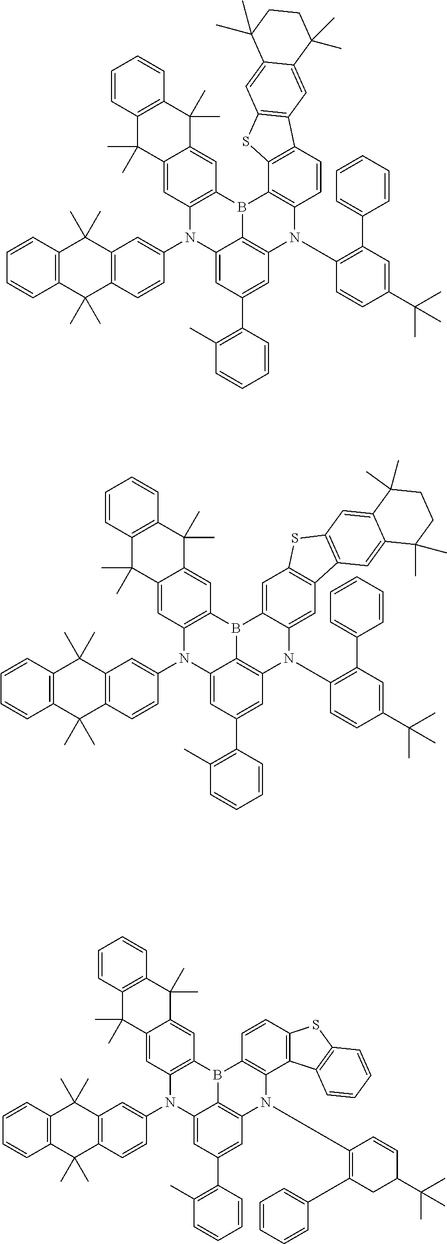 [SMILES: Cc1ccccc1-c1cc2c3c(c1)N(c1ccc(C(C)(C)C)cc1-c1ccccc1)c1ccc4c(sc5cc6c(cc54)C(C)(C)CCC6(C)C)c1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1cc2c(cc14)C(C)(C)CCC2(C)C ; Cc1ccccc1-c1cc2c3c(c1)N(c1ccc4c(c1)C(C)(C)c1ccccc1C4(C)C)c1cc4c(cc1B3c1ccc3sc5ccccc5c3c1N2C1=C(c2ccccc2)CC(C(C)(C)C)C=C1)C(C)(C)c1ccccc1C4(C)C]

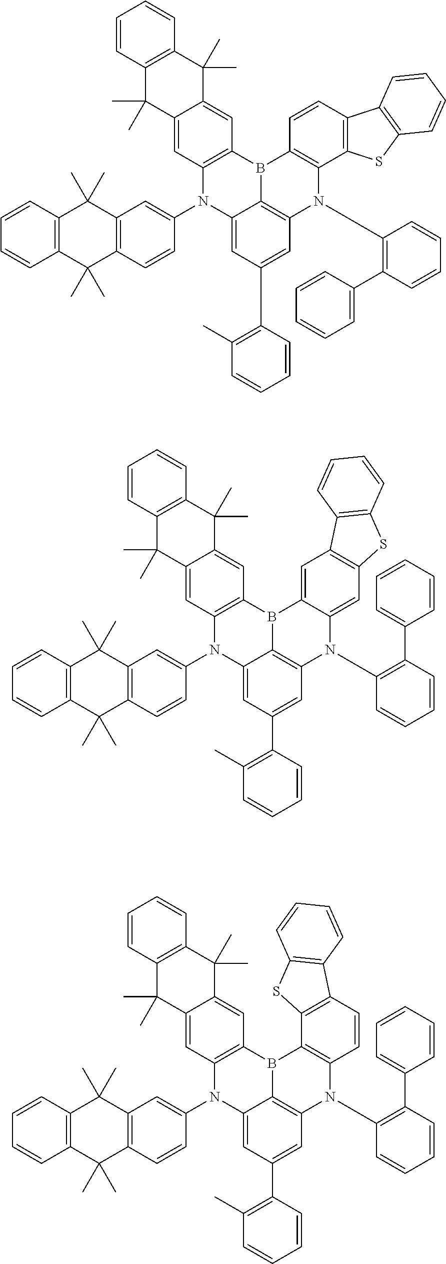 [SMILES: Cc1ccccc1-c1cc2c3c(c1)N(c1ccccc1-c1ccccc1)c1c(ccc4c1sc1ccccc14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1cc4sc5ccccc5c4cc1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1ccc4c(sc5ccccc54)c1B3c1cc3c(cc1N2c1ccc2c(c1)C(C)(C)c1ccccc1C2(C)C)C(C)(C)c1ccccc1C3(C)C]

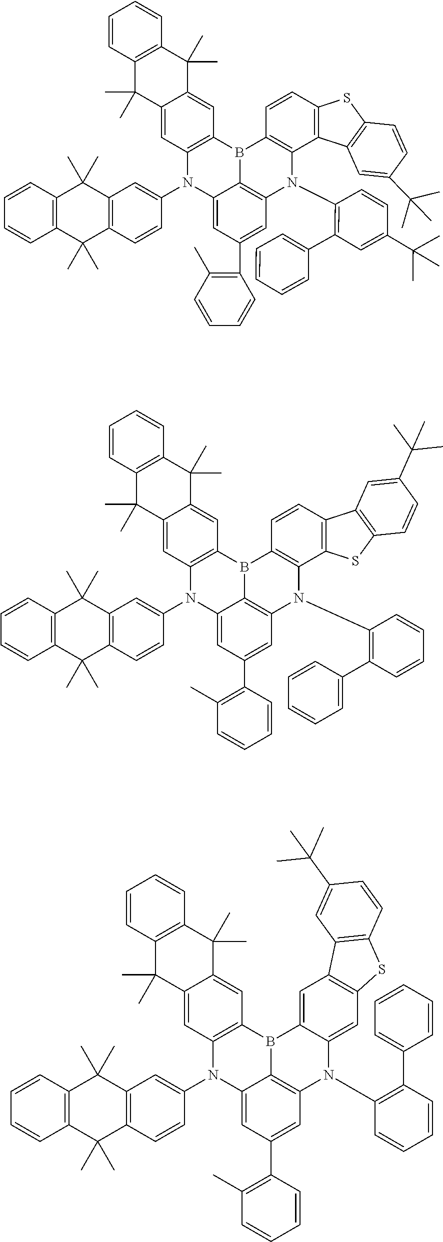 [SMILES: Cc1ccccc1-c1cc2c3c(c1)N(c1ccc(C(C)(C)C)cc1-c1ccccc1)c1c(ccc4sc5ccc(C(C)(C)C)cc5c14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1c(ccc4c1sc1ccc(C(C)(C)C)cc14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1cc4sc5ccc(C(C)(C)C)cc5c4cc1B3c1cc3c(cc1N2c1ccc2c(c1)C(C)(C)c1ccccc1C2(C)C)C(C)(C)c1ccccc1C3(C)C]

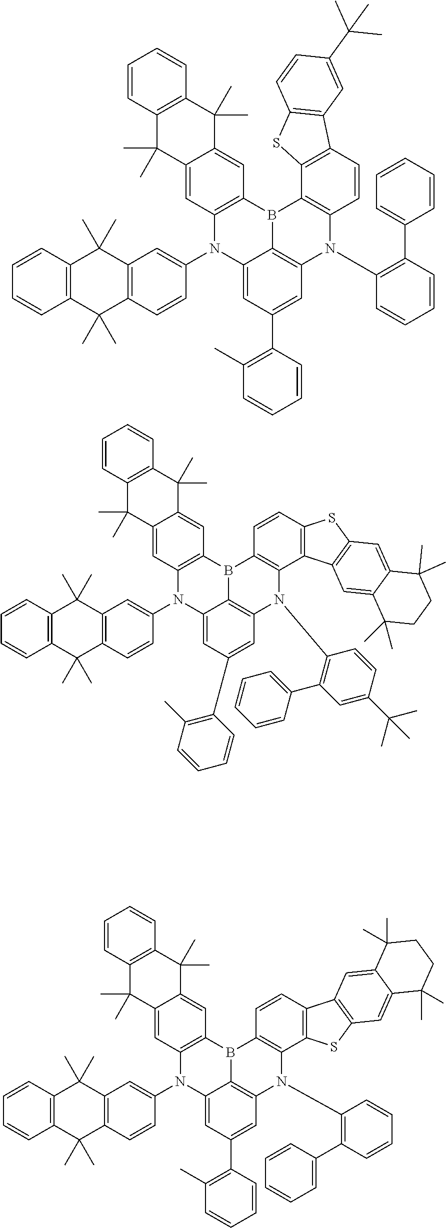 [SMILES: Cc1ccccc1-c1cc2c3c(c1)N(c1ccccc1-c1ccccc1)c1ccc4c(sc5ccc(C(C)(C)C)cc54)c1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1c(ccc4c1sc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C]

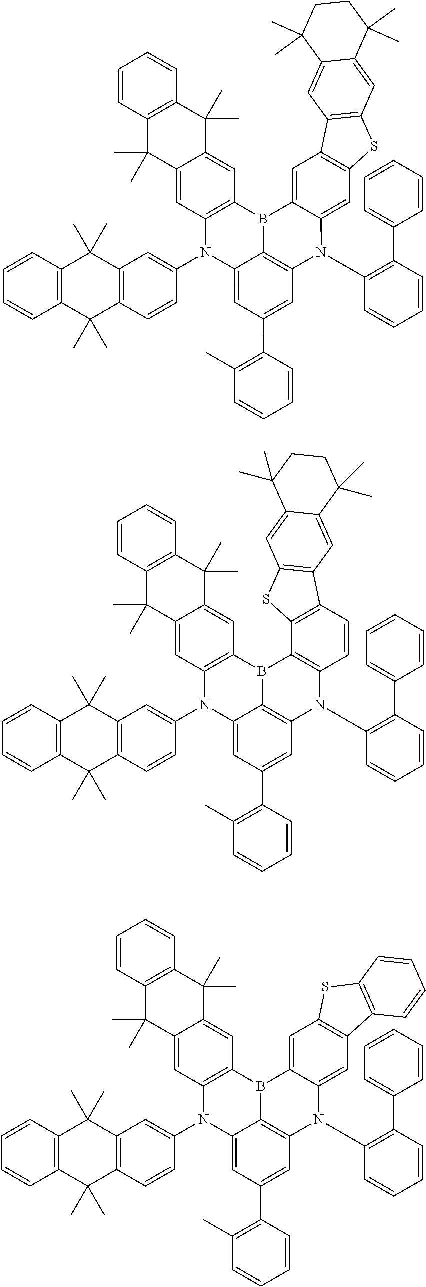

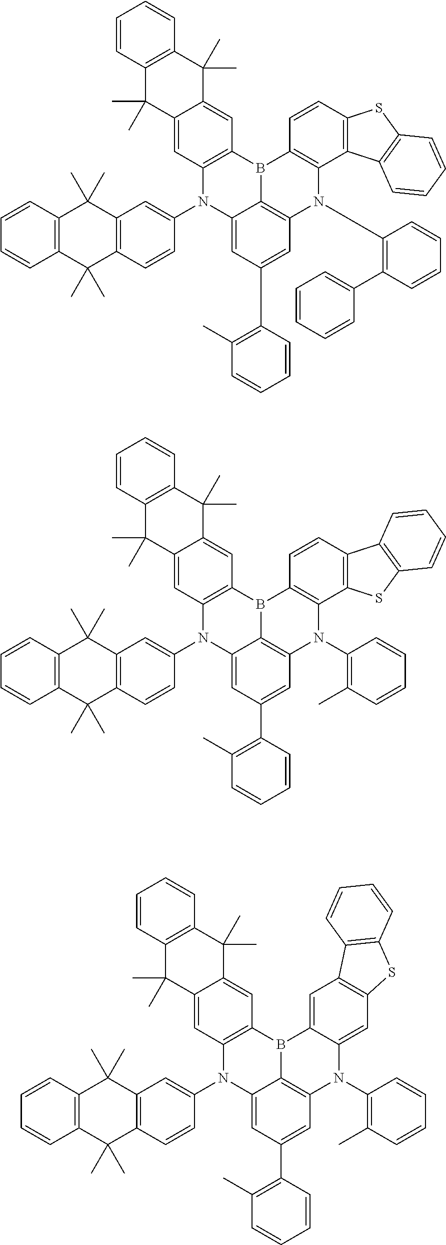 [SMILES: Cc1ccccc1-c1cc2c3c(c1)N(c1ccccc1-c1ccccc1)c1c(ccc4sc5ccccc5c14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1c(ccc4c1sc1ccccc14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1cc4sc5ccccc5c4cc1B3c1cc3c(cc1N2c1ccc2c(c1)C(C)(C)c1ccccc1C2(C)C)C(C)(C)c1ccccc1C3(C)C]

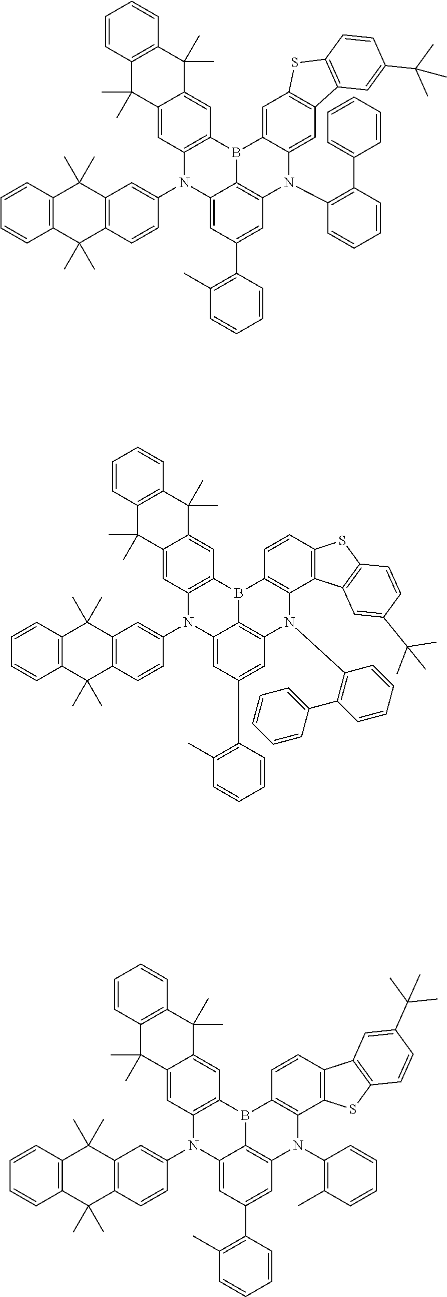 [SMILES: Cc1ccccc1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1ccc(C(C)(C)C)cc14 ; Cc1ccccc1-c1cc2c3c(c1)N(c1ccccc1-c1ccccc1)c1c(ccc4sc5ccc(C(C)(C)C)cc5c14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1c(ccc4c1sc1ccc(C(C)(C)C)cc14)B3c1cc3c(cc1N2c1ccc2c(c1)C(C)(C)c1ccccc1C2(C)C)C(C)(C)c1ccccc1C3(C)C]

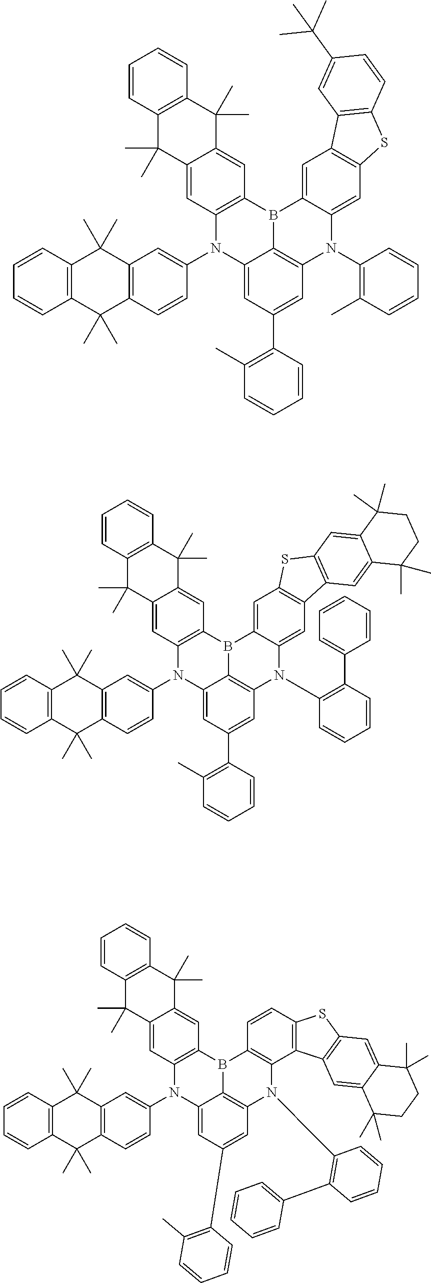 [SMILES: Cc1ccccc1-c1cc2c3c(c1)N(c1ccccc1C)c1cc4sc5ccc(C(C)(C)C)cc5c4cc1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1cc2c(cc14)C(C)(C)CCC2(C)C ; Cc1ccccc1-c1cc2c3c(c1)N(c1ccccc1-c1ccccc1)c1c(ccc4sc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C]

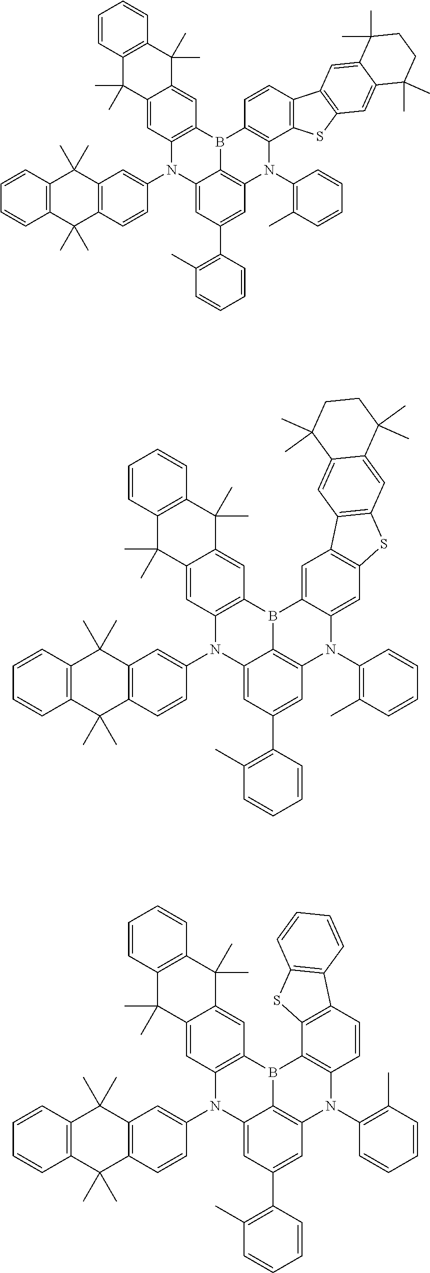 [SMILES: Cc1ccccc1-c1cc2c3c(c1)N(c1ccccc1C)c1c(ccc4c1sc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1cc4sc5cc6c(cc5c4cc1B3c1cc3c(cc1N2c1ccc2c(c1)C(C)(C)c1ccccc1C2(C)C)C(C)(C)c1ccccc1C3(C)C)C(C)(C)CCC6(C)C ; Cc1ccccc1-c1cc2c3c(c1)N(c1ccccc1C)c1ccc4c(sc5ccccc54)c1B3c1cc3c(cc1N2c1ccc2c(c1)C(C)(C)c1ccccc1C2(C)C)C(C)(C)c1ccccc1C3(C)C]

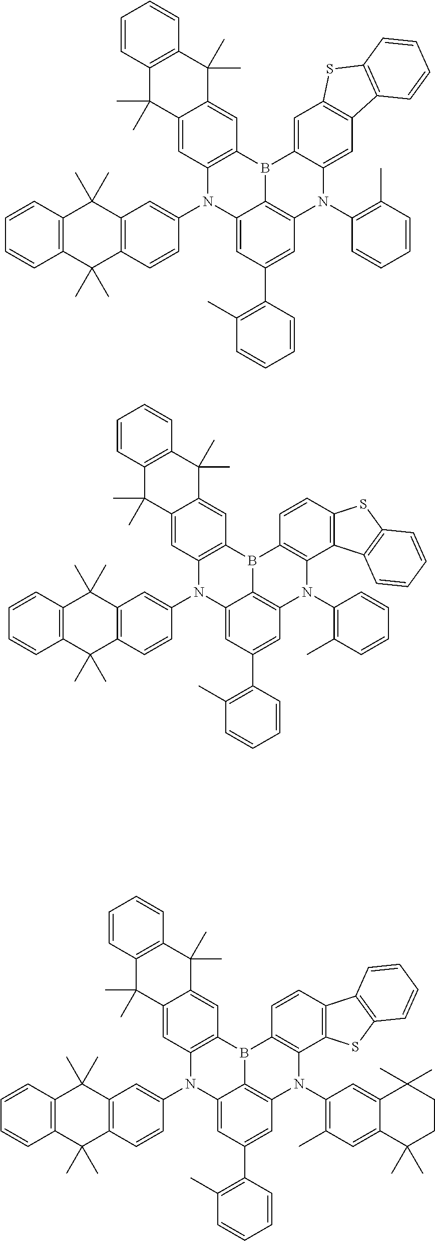 [SMILES: Cc1ccccc1-c1cc2c3c(c1)N(c1ccccc1C)c1cc4c(cc1B3c1cc3c(cc1N2c1ccc2c(c1)C(C)(C)c1ccccc1C2(C)C)C(C)(C)c1ccccc1C3(C)C)sc1ccccc14 ; Cc1ccccc1-c1cc2c3c(c1)N(c1ccccc1C)c1c(ccc4sc5ccccc5c14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1sc1ccccc14)B3c1cc3c(cc1N2c1ccc2c(c1)C(C)(C)c1ccccc1C2(C)C)C(C)(C)c1ccccc1C3(C)C]

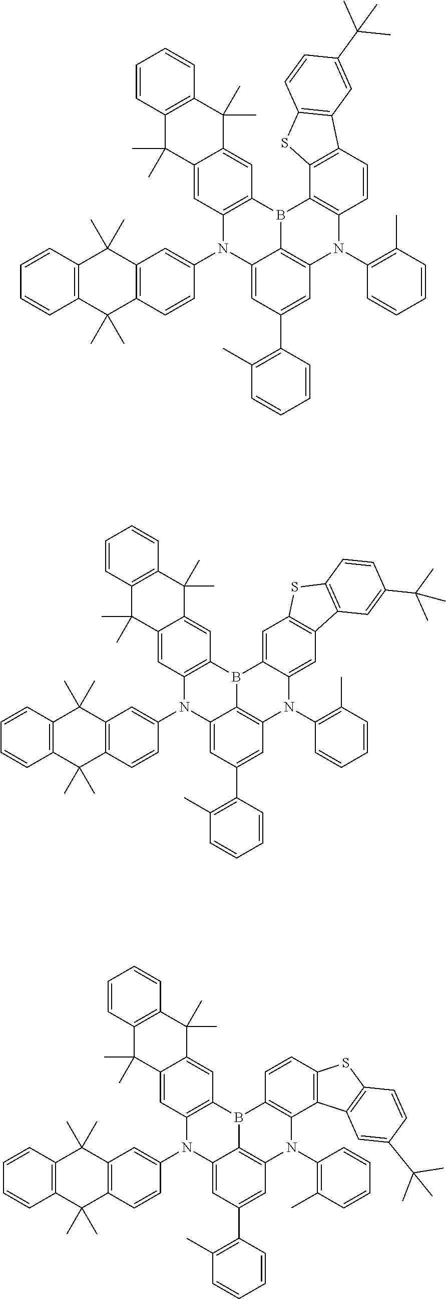 [SMILES: Cc1ccccc1-c1cc2c3c(c1)N(c1ccccc1C)c1ccc4c(sc5ccc(C(C)(C)C)cc54)c1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1cc4c(cc1B3c1cc3c(cc1N2c1ccc2c(c1)C(C)(C)c1ccccc1C2(C)C)C(C)(C)c1ccccc1C3(C)C)sc1ccc(C(C)(C)C)cc14 ; Cc1ccccc1-c1cc2c3c(c1)N(c1ccccc1C)c1c(ccc4sc5ccc(C(C)(C)C)cc5c14)B3c1cc3c(cc1N2c1ccc2c(c1)C(C)(C)c1ccccc1C2(C)C)C(C)(C)c1ccccc1C3(C)C]

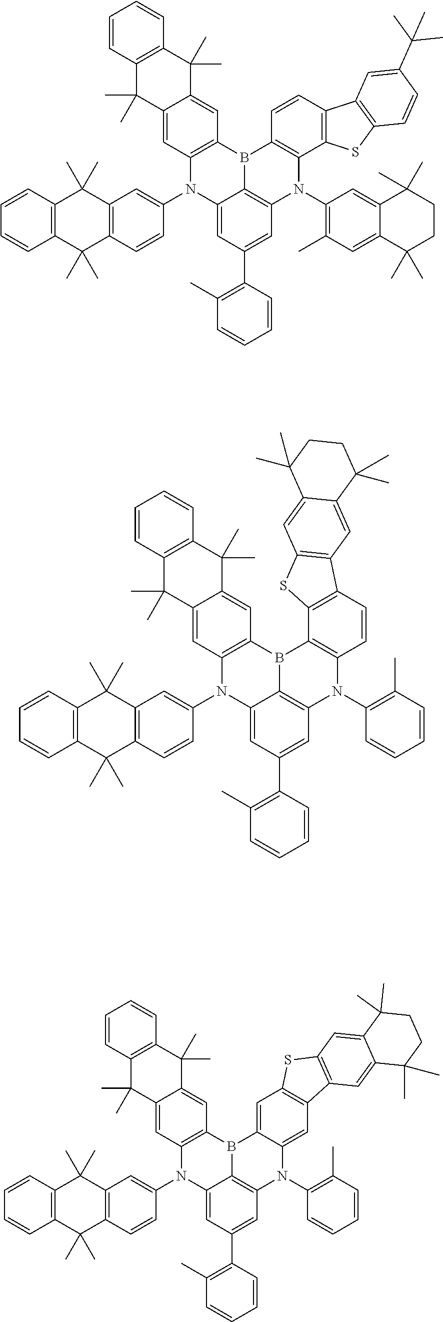 [SMILES: Cc1ccccc1-c1cc2c3c(c1)N(c1cc4c(cc1C)C(C)(C)CCC4(C)C)c1c(ccc4c1sc1ccc(C(C)(C)C)cc14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1ccc4c(sc5cc6c(cc54)C(C)(C)CCC6(C)C)c1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1C)c1cc4c(cc1B3c1cc3c(cc1N2c1ccc2c(c1)C(C)(C)c1ccccc1C2(C)C)C(C)(C)c1ccccc1C3(C)C)sc1cc2c(cc14)C(C)(C)CCC2(C)C]

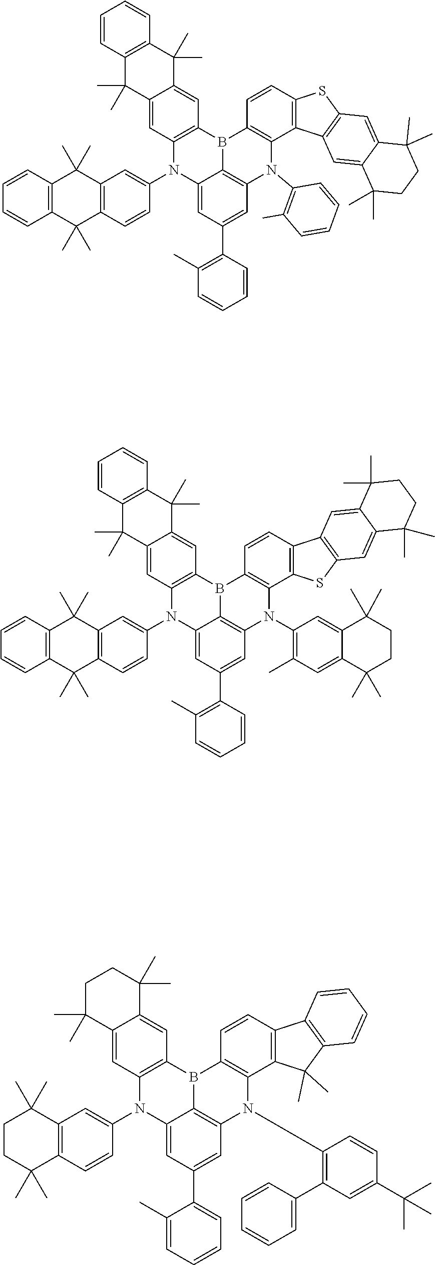 [SMILES: Cc1ccccc1-c1cc2c3c(c1)N(c1ccccc1C)c1c(ccc4sc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1c(ccc4c1C(C)(C)c1ccccc1-4)B3c1cc3c(cc1N2c1ccc2c(c1)C(C)(C)CCC2(C)C)C(C)(C)CCC3(C)C]

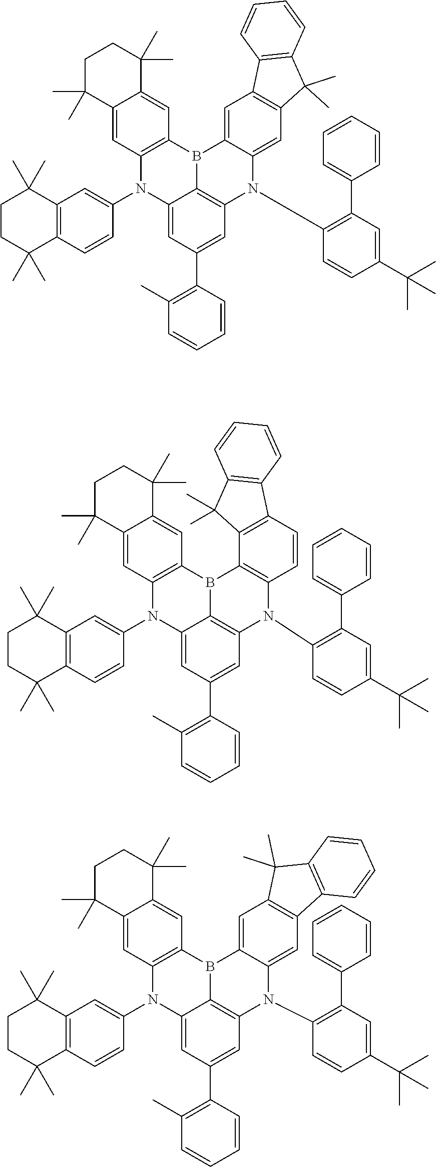 [SMILES: Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)-c1ccccc1C4(C)C ; Cc1ccccc1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1ccccc1-4 ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1ccccc1-4]

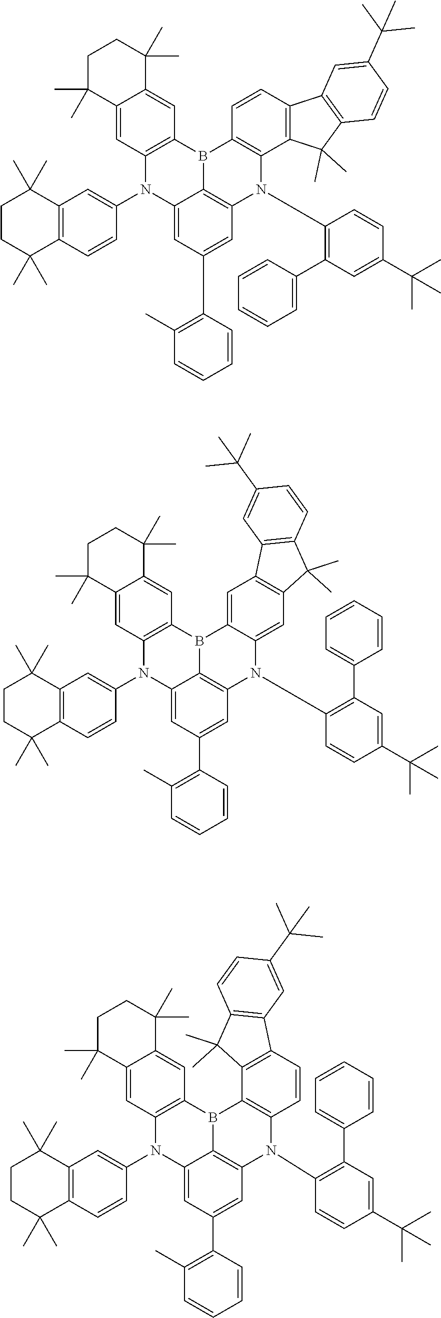 [SMILES: Cc1ccccc1-c1cc2c3c(c1)N(c1ccc(C(C)(C)C)cc1-c1ccccc1)c1c(ccc4c1C(C)(C)c1ccc(C(C)(C)C)cc1-4)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)-c1cc(C(C)(C)C)ccc1C4(C)C ; Cc1ccccc1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1ccc(C(C)(C)C)cc1-4]

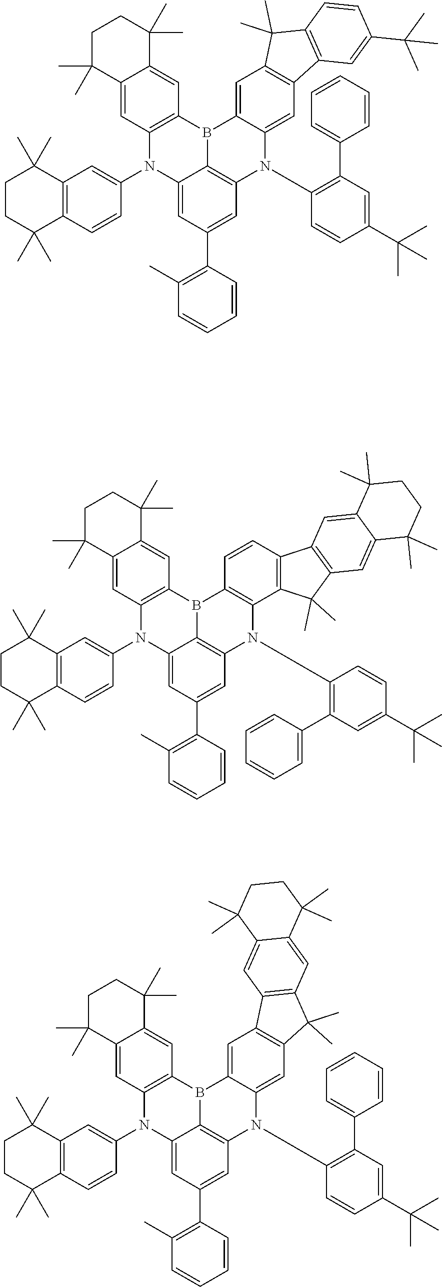 [SMILES: Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)-c1cc2c(cc1C4(C)C)C(C)(C)CCC2(C)C]

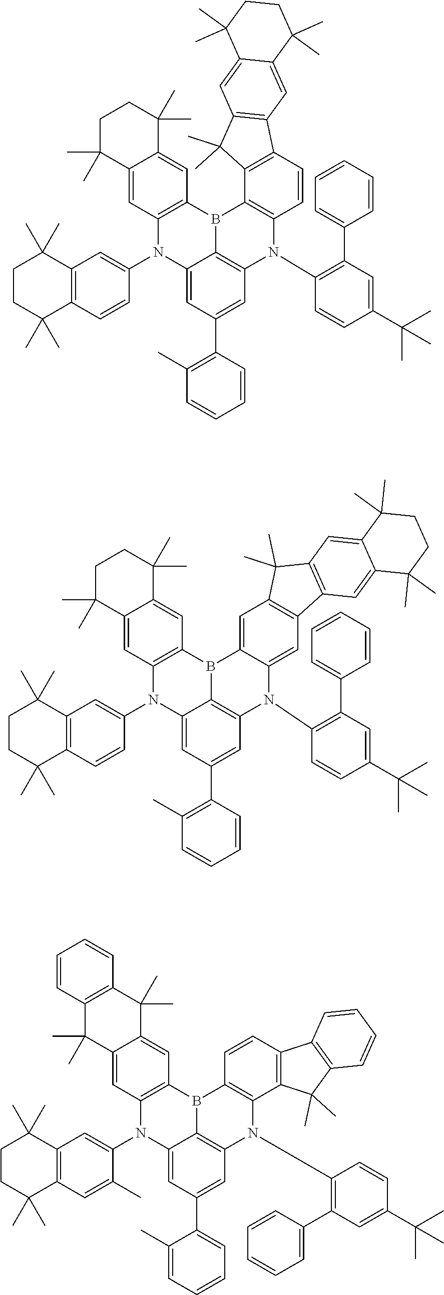 [SMILES: Cc1ccccc1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C ; Cc1ccccc1-c1cc2c3c(c1)N(c1ccc(C(C)(C)C)cc1-c1ccccc1)c1c(ccc4c1C(C)(C)c1ccccc1-4)B3c1cc3c(cc1N2c1cc2c(cc1C)C(C)(C)CCC2(C)C)C(C)(C)c1ccccc1C3(C)C]

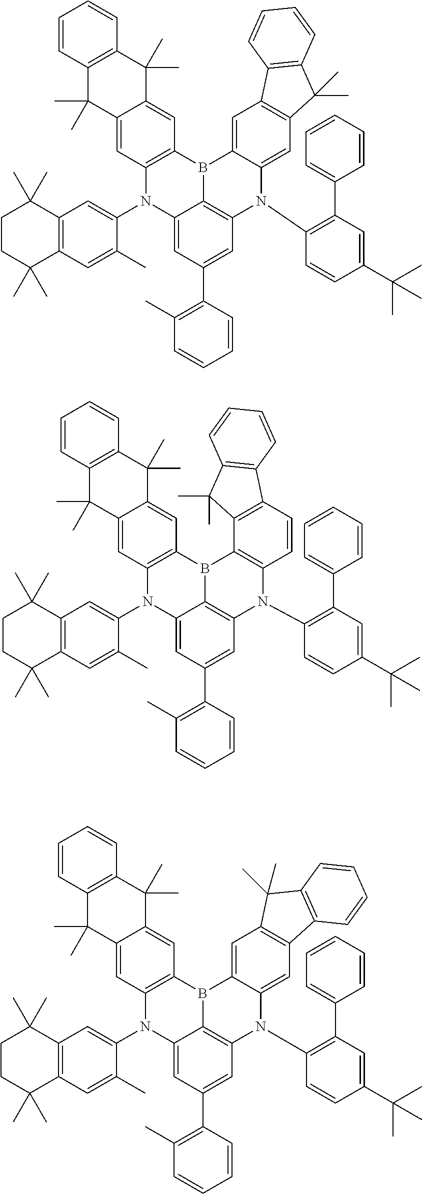 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)-c1ccccc1C4(C)C ; Cc1ccccc1-c1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)c1ccccc1C3(C)C)C(C)(C)c1ccccc1-4 ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)C(C)(C)c1ccccc1-4]

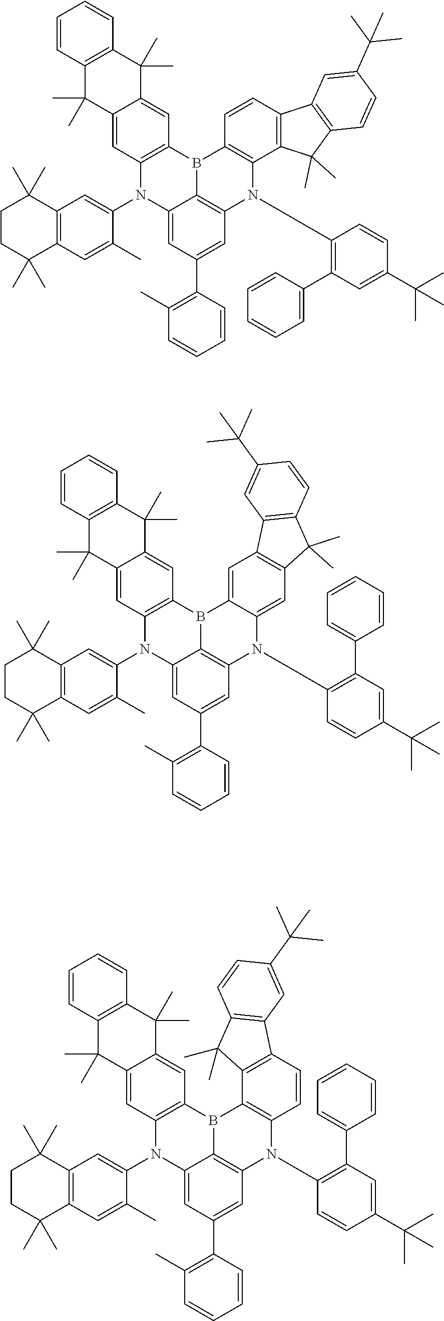 [SMILES: Cc1ccccc1-c1cc2c3c(c1)N(c1ccc(C(C)(C)C)cc1-c1ccccc1)c1c(ccc4c1C(C)(C)c1ccc(C(C)(C)C)cc1-4)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)-c1cc(C(C)(C)C)ccc1C4(C)C ; Cc1ccccc1-c1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)c1ccccc1C3(C)C)C(C)(C)c1ccc(C(C)(C)C)cc1-4]

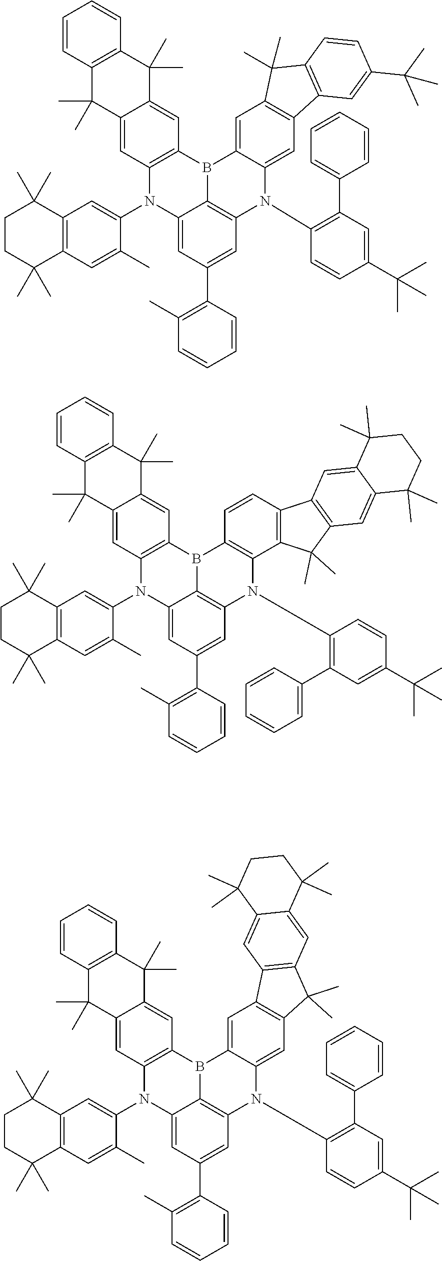 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)-c1cc2c(cc1C4(C)C)C(C)(C)CCC2(C)C]

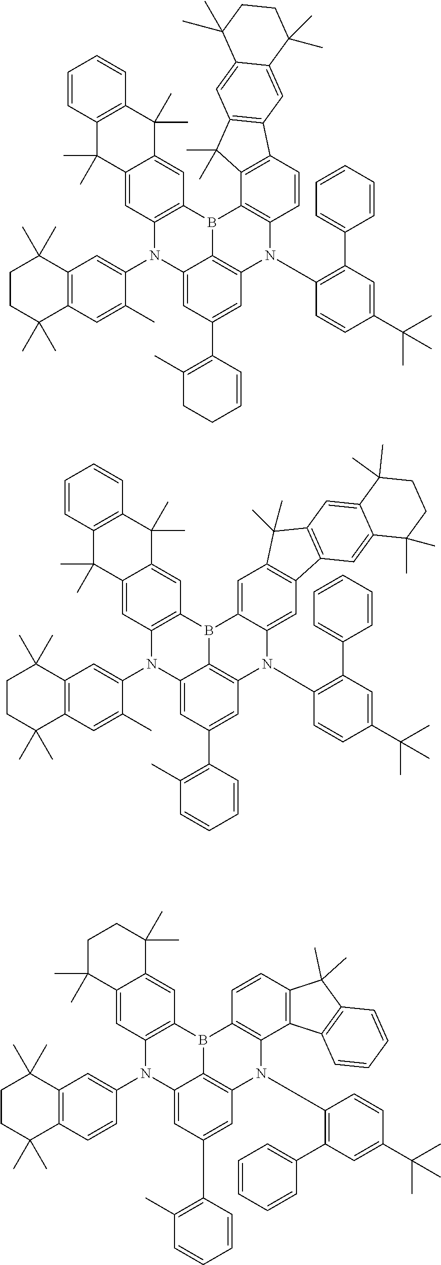 [SMILES: CC1=C(c2cc3c4c(c2)N(c2ccc(C(C)(C)C)cc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2cc3c(cc2-5)C(C)(C)CCC3(C)C)C=CCC1 ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)C(C)(C)c1cc2c(cc1-4)C(C)(C)CCC2(C)C ; Cc1ccccc1-c1cc2c3c(c1)N(c1ccc(C(C)(C)C)cc1-c1ccccc1)c1c(ccc4c1-c1ccccc1C4(C)C)B3c1cc3c(cc1N2c1ccc2c(c1)C(C)(C)CCC2(C)C)C(C)(C)CCC3(C)C]

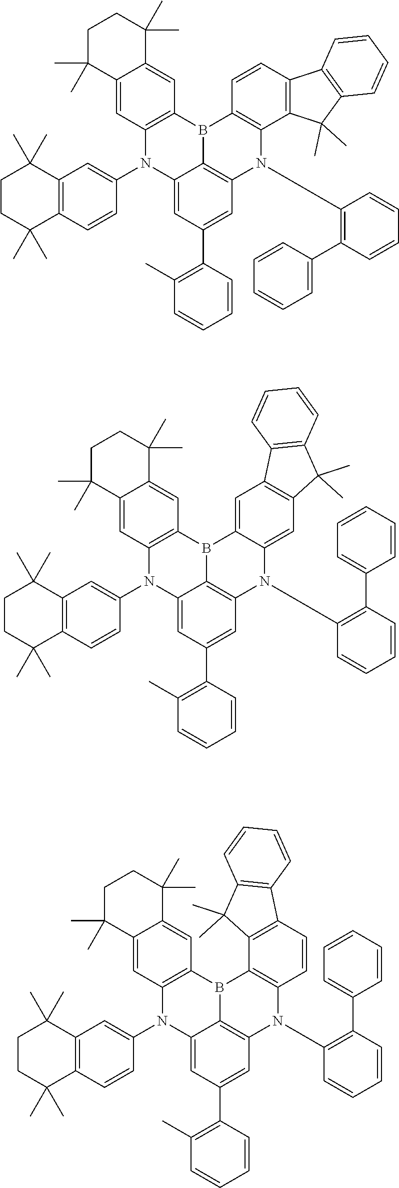 [SMILES: Cc1ccccc1-c1cc2c3c(c1)N(c1ccccc1-c1ccccc1)c1c(ccc4c1C(C)(C)c1ccccc1-4)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)-c1ccccc1C4(C)C ; Cc1ccccc1-c1cc2c3c(c1)N(c1ccccc1-c1ccccc1)c1ccc4c(c1B3c1cc3c(cc1N2c1ccc2c(c1)C(C)(C)CCC2(C)C)C(C)(C)CCC3(C)C)C(C)(C)c1ccccc1-4]

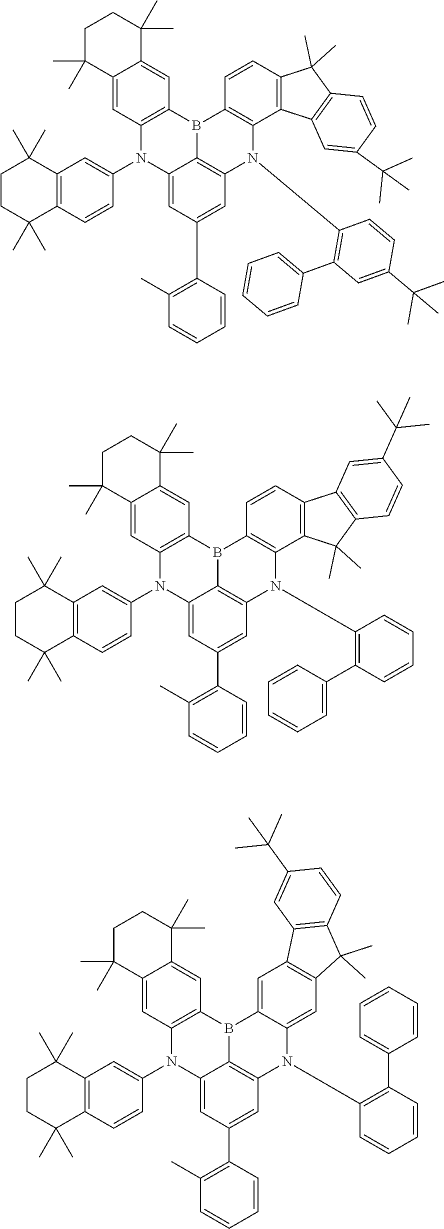 [SMILES: Cc1ccccc1-c1cc2c3c(c1)N(c1ccc(C(C)(C)C)cc1-c1ccccc1)c1c(ccc4c1-c1cc(C(C)(C)C)ccc1C4(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1C(C)(C)c1ccc(C(C)(C)C)cc1-4)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)-c1cc(C(C)(C)C)ccc1C4(C)C]

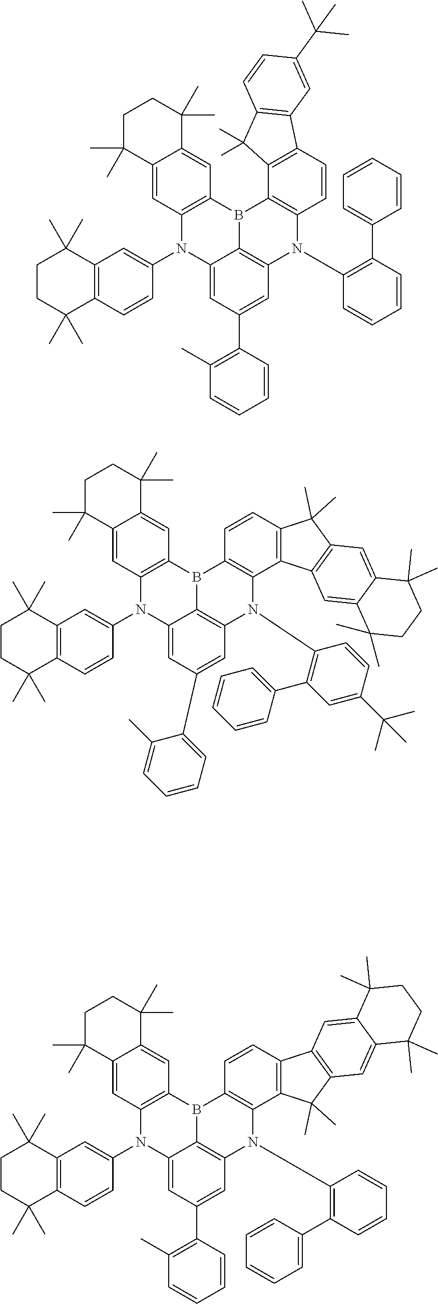 [SMILES: Cc1ccccc1-c1cc2c3c(c1)N(c1ccccc1-c1ccccc1)c1ccc4c(c1B3c1cc3c(cc1N2c1ccc2c(c1)C(C)(C)CCC2(C)C)C(C)(C)CCC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1ccc2c(c1)C(C)(C)CCC2(C)C)C(C)(C)CCC3(C)C]

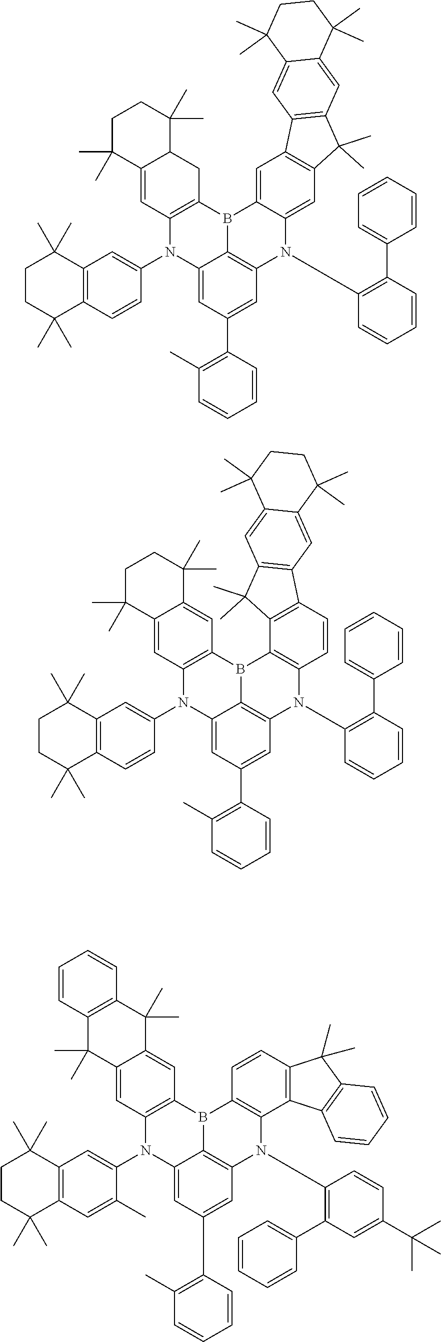

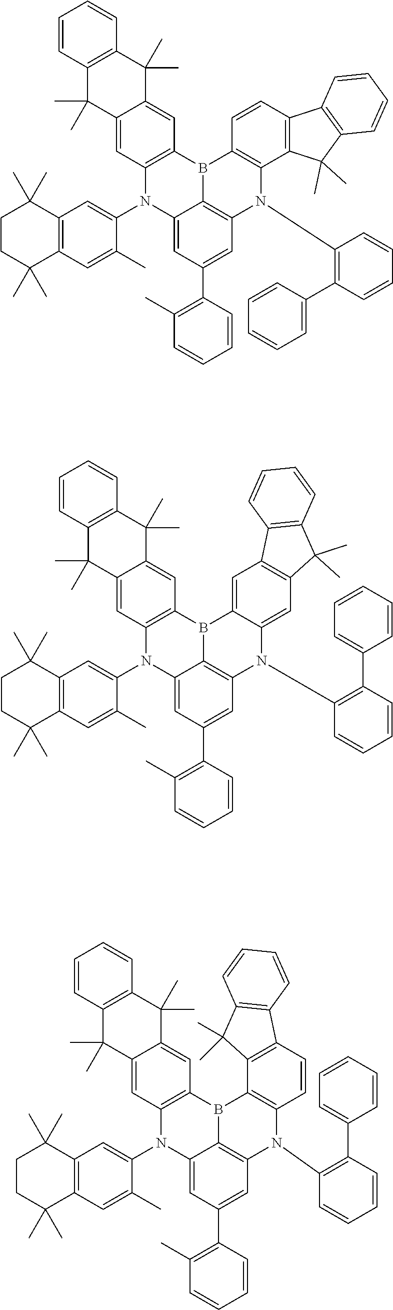 [SMILES: Cc1ccccc1-c1cc2c3c(c1)N(c1ccccc1-c1ccccc1)c1c(ccc4c1C(C)(C)c1ccccc1-4)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)-c1ccccc1C4(C)C ; Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)c1ccccc1C3(C)C)C(C)(C)c1ccccc1-4]

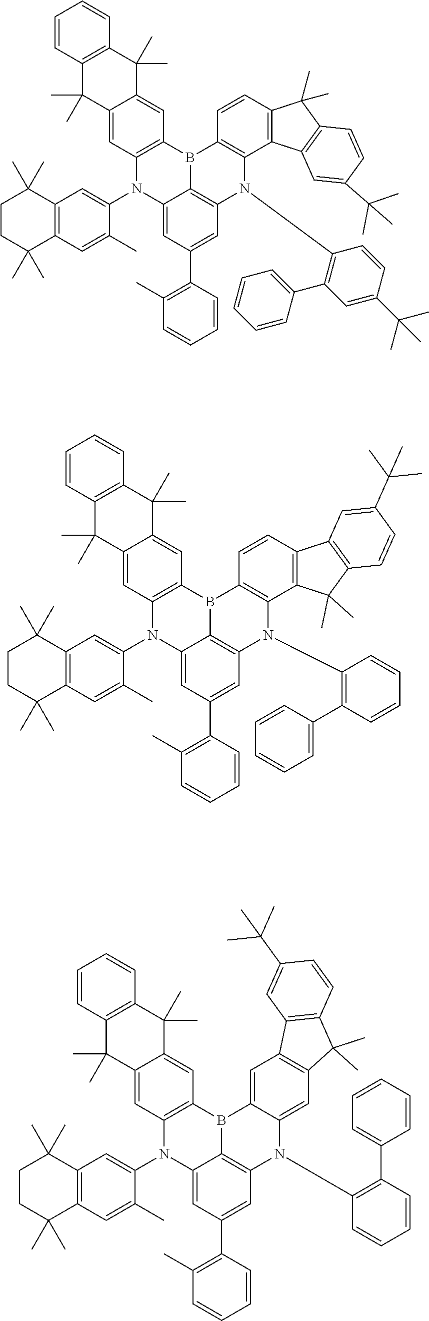 [SMILES: Cc1ccccc1-c1cc2c3c(c1)N(c1ccc(C(C)(C)C)cc1-c1ccccc1)c1c(ccc4c1-c1cc(C(C)(C)C)ccc1C4(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1C(C)(C)c1ccc(C(C)(C)C)cc1-4)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)-c1cc(C(C)(C)C)ccc1C4(C)C]

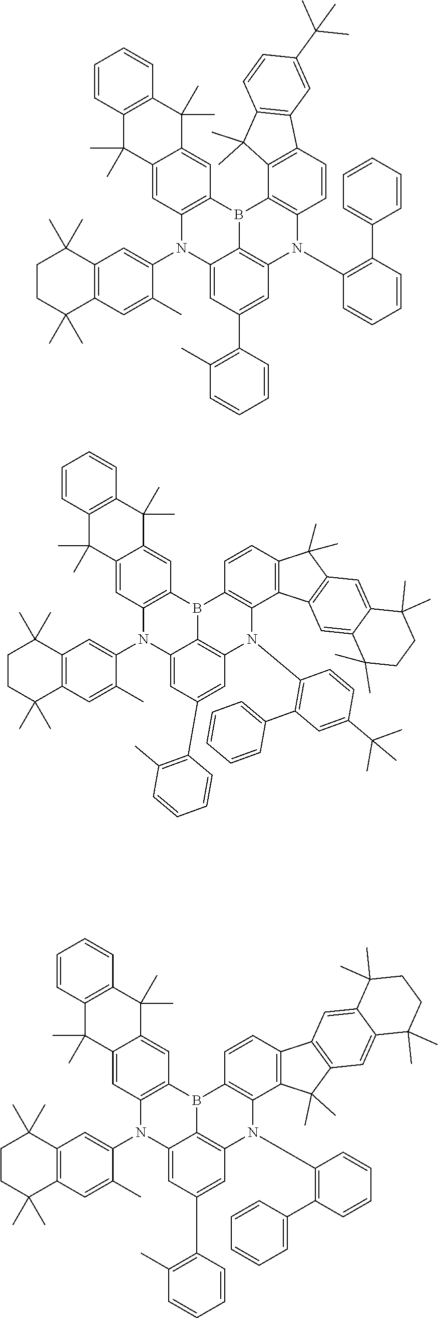 [SMILES: Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)c1ccccc1C3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)c1ccccc1C3(C)C]

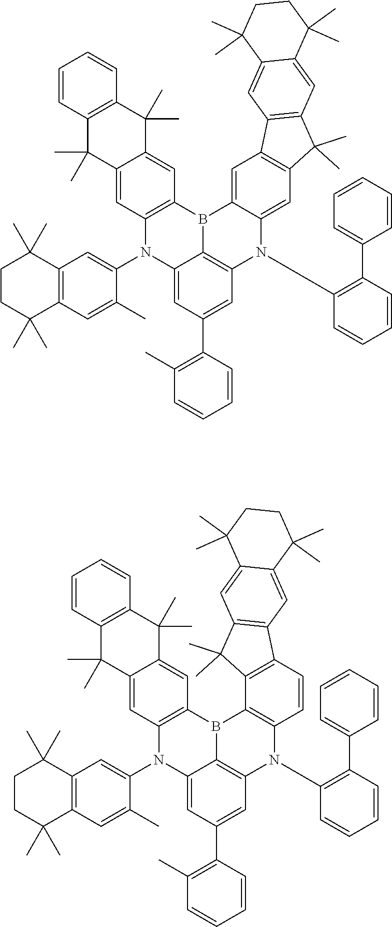 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)-c1cc2c(cc1C4(C)C)C(C)(C)CCC2(C)C ; Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)c1ccccc1C3(C)C)C(C)(C)c1cc2c(cc1-4)C(C)(C)CCC2(C)C]

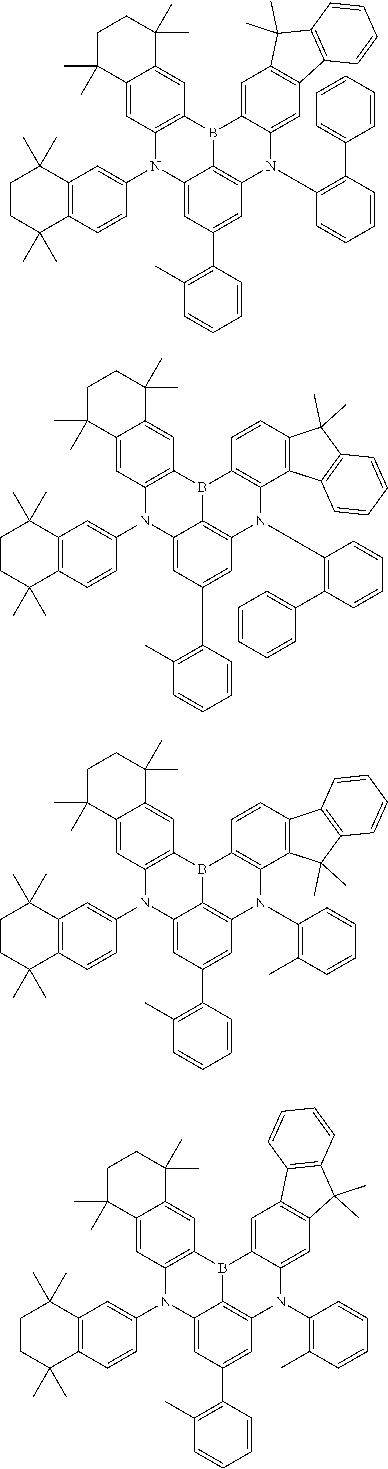 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)C(C)(C)c1ccccc1-4 ; Cc1ccccc1-c1cc2c3c(c1)N(c1ccccc1-c1ccccc1)c1c(ccc4c1-c1ccccc1C4(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1c(ccc4c1C(C)(C)c1ccccc1-4)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4c(cc1B3c1cc3c(cc1N2c1ccc2c(c1)C(C)(C)CCC2(C)C)C(C)(C)CCC3(C)C)-c1ccccc1C4(C)C]

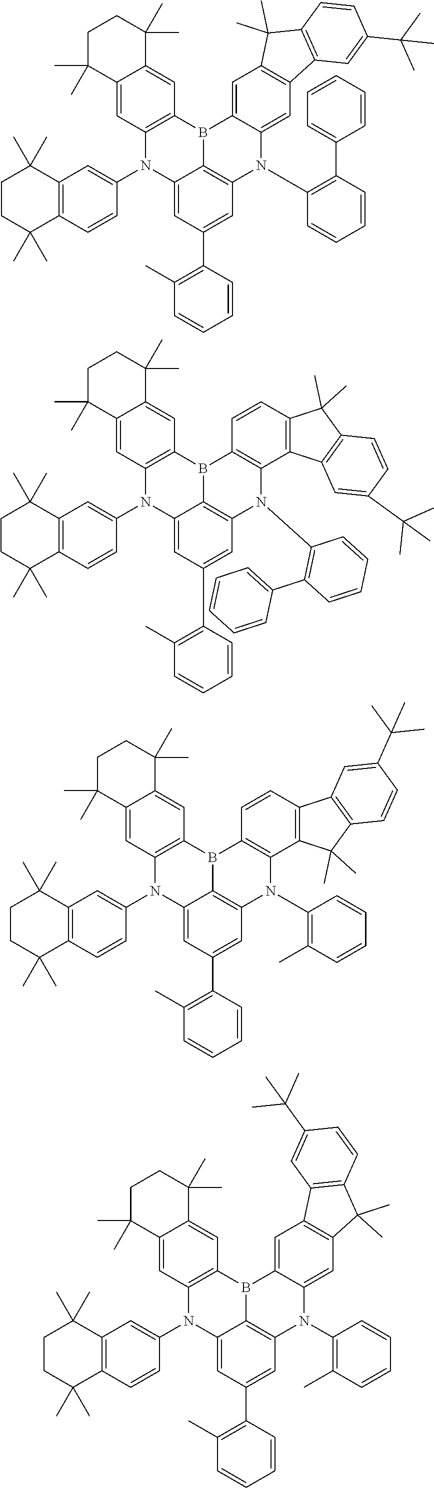

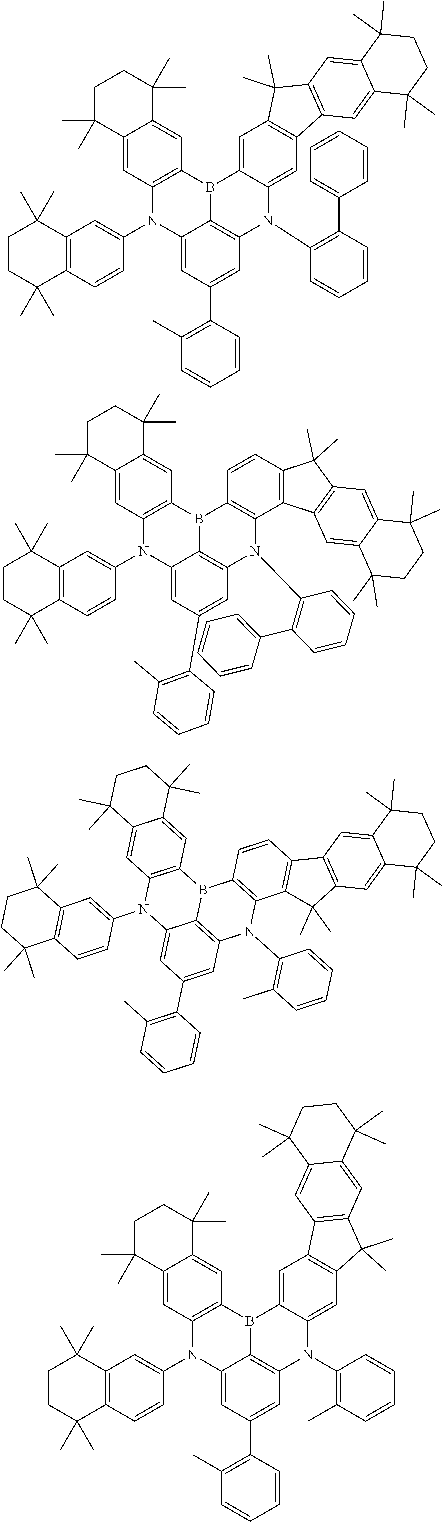

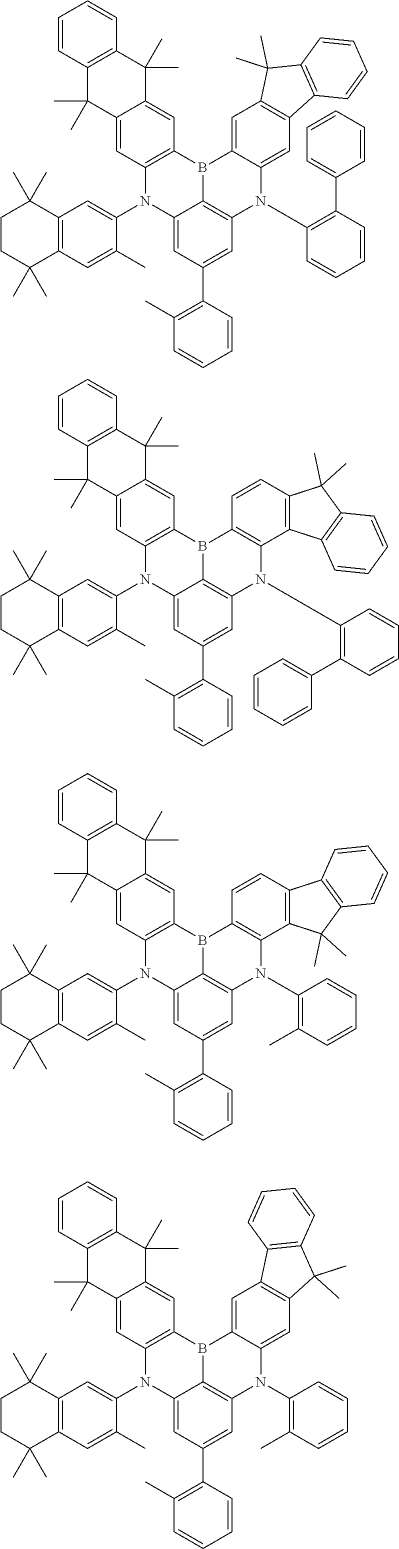

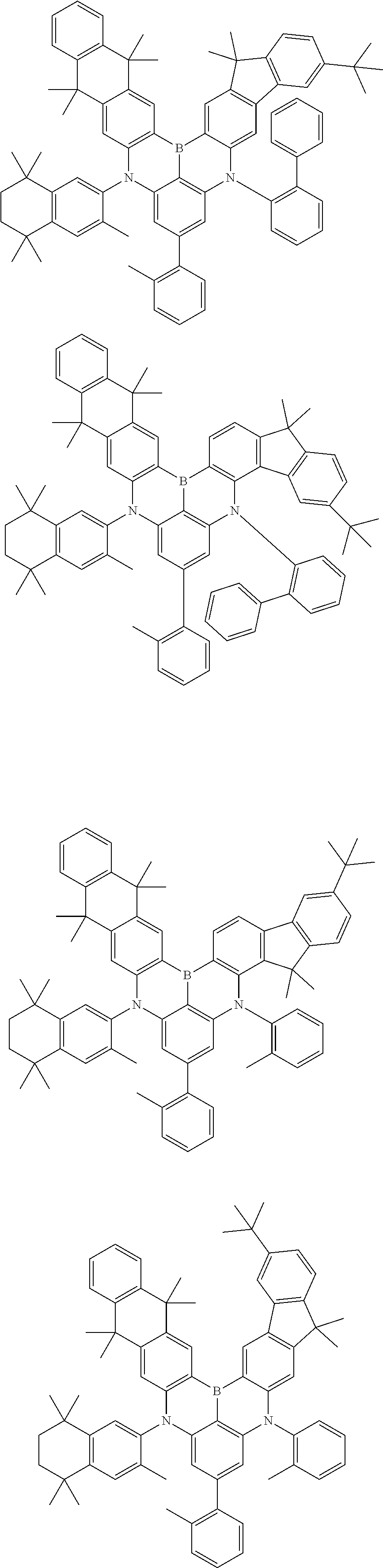

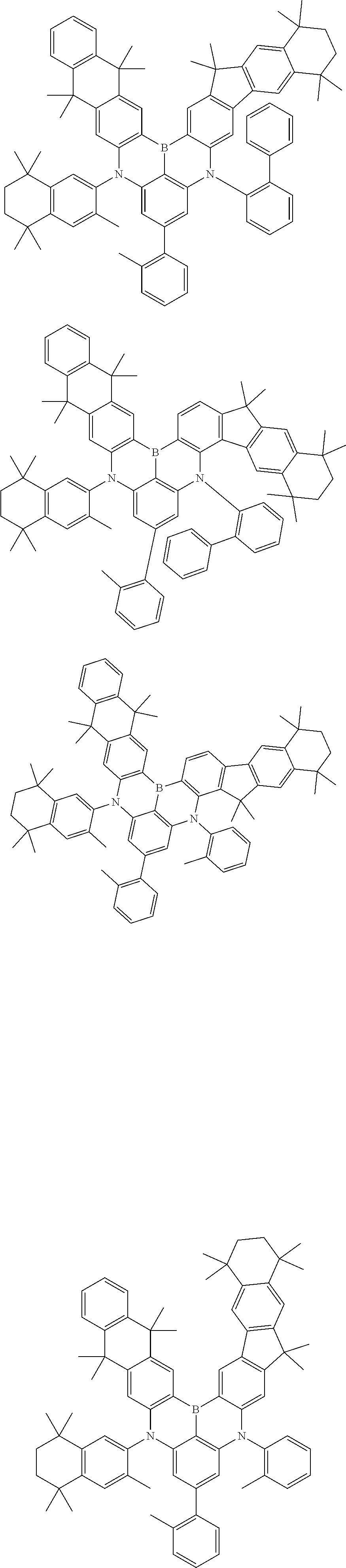

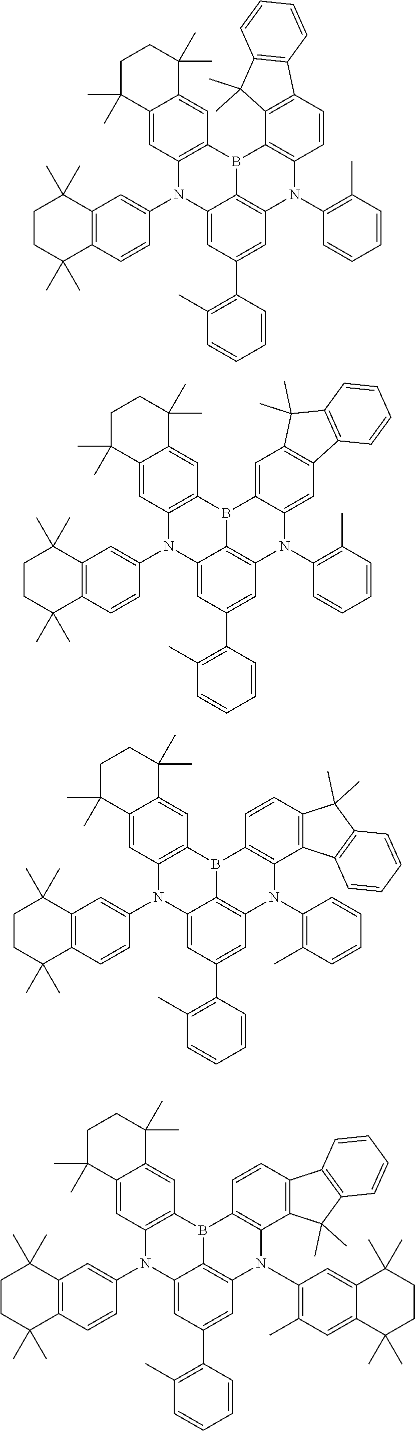

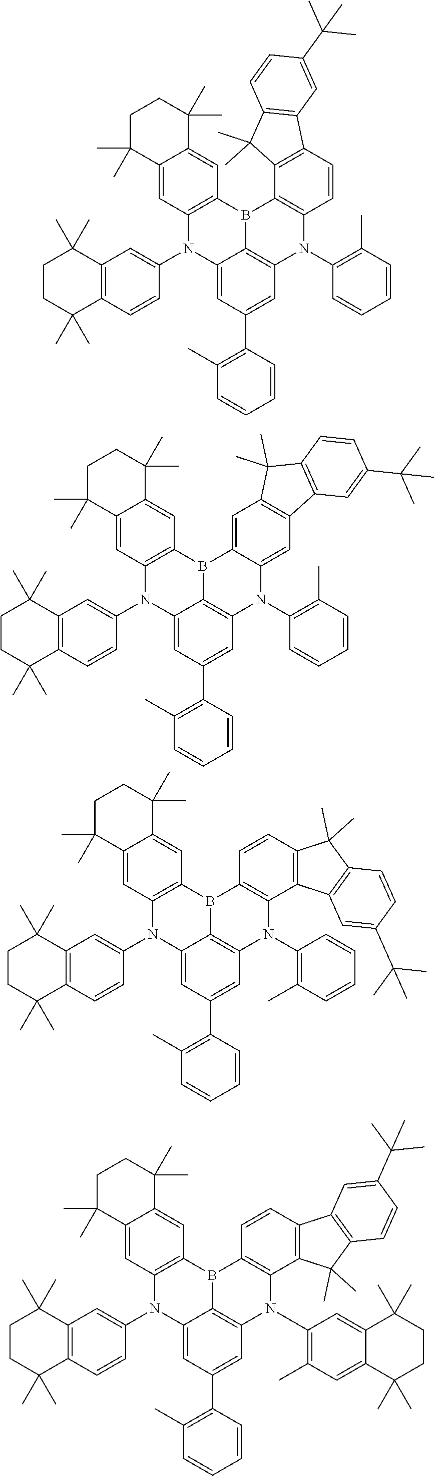

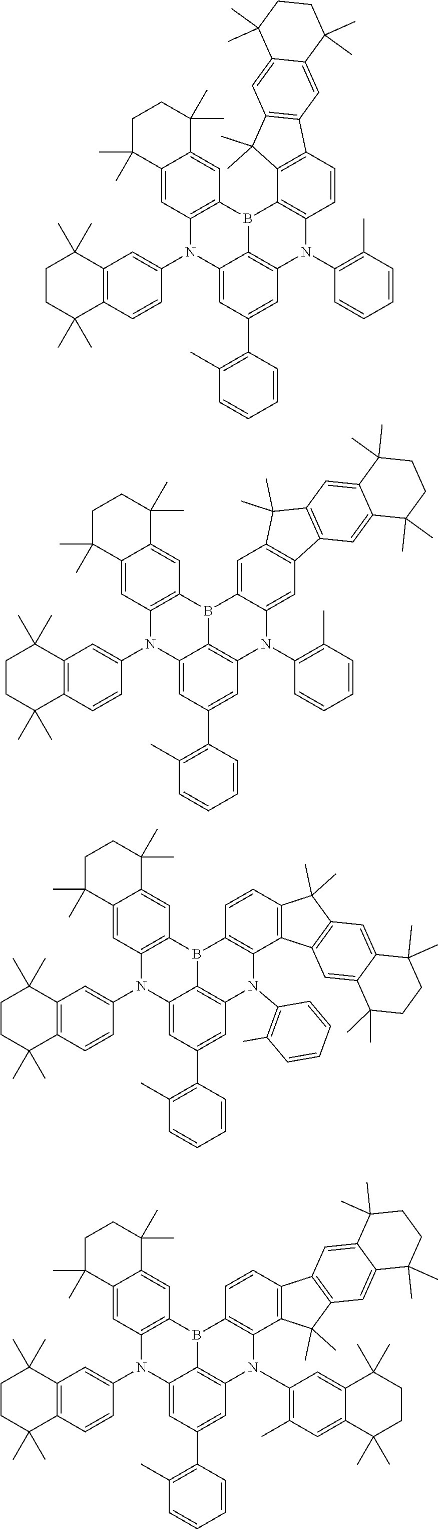

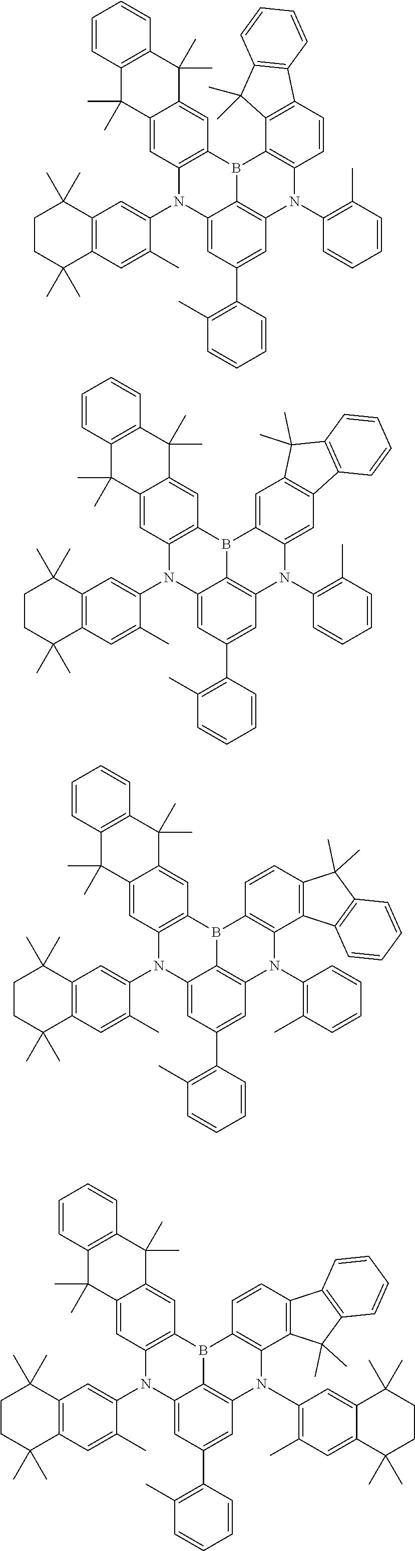

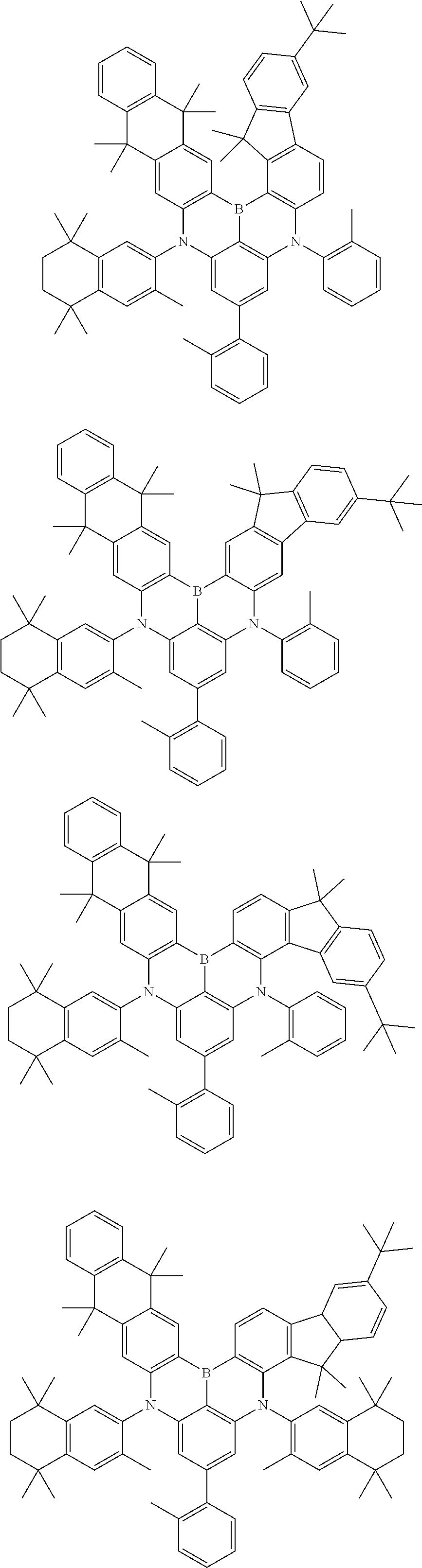

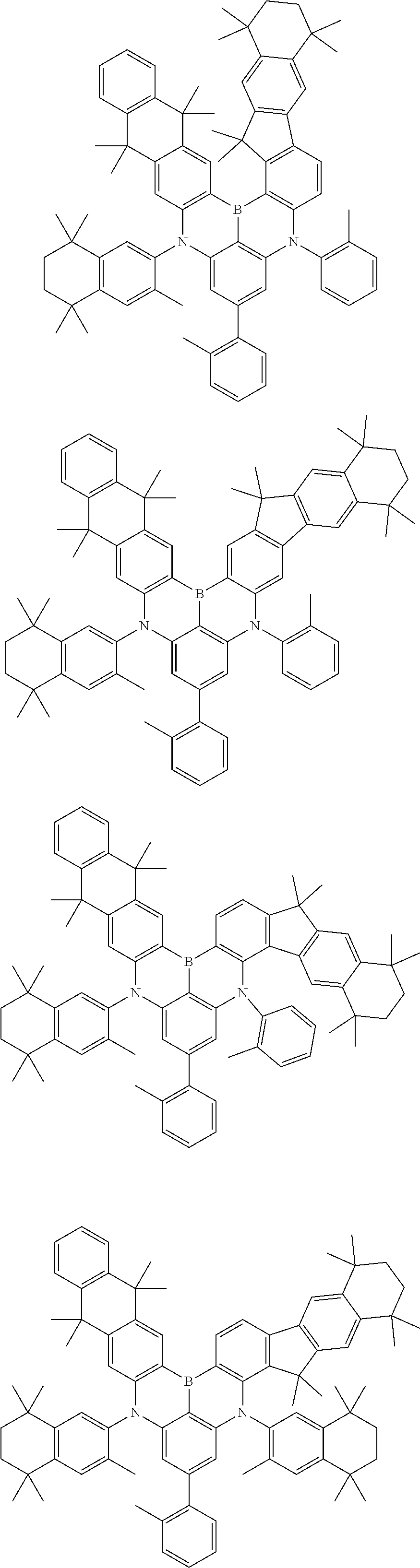

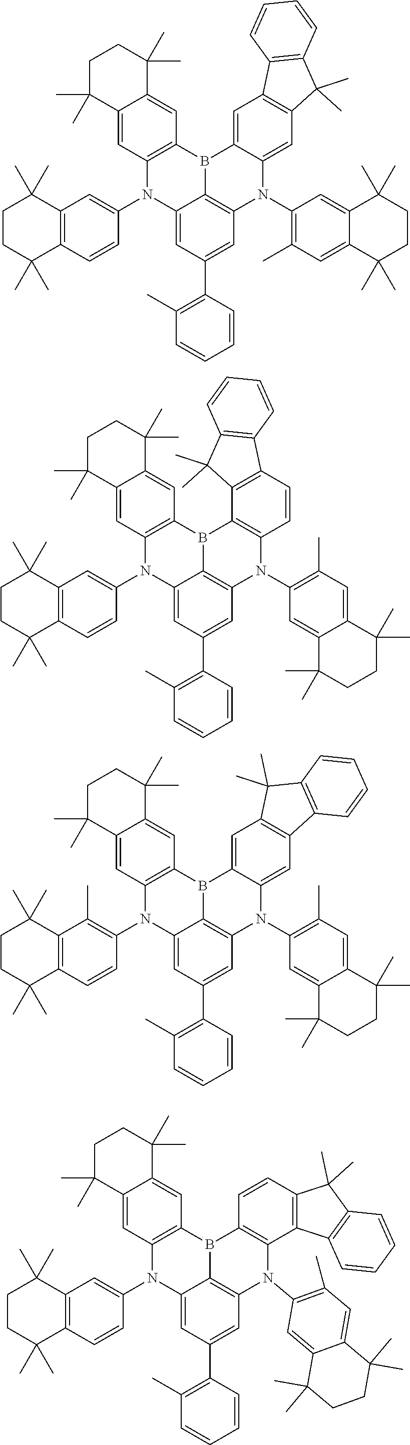

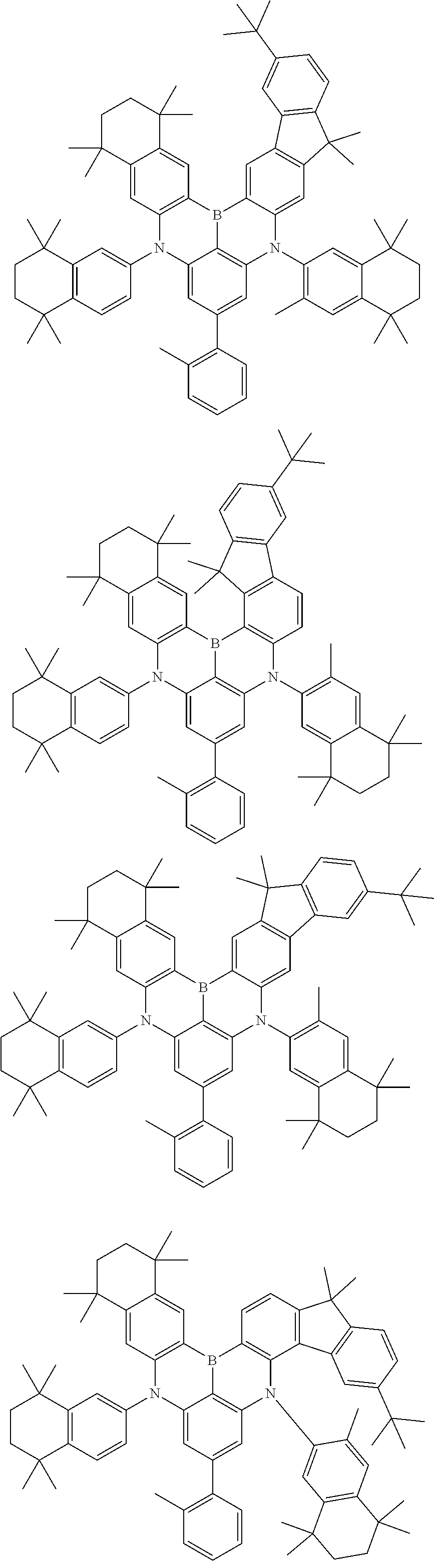

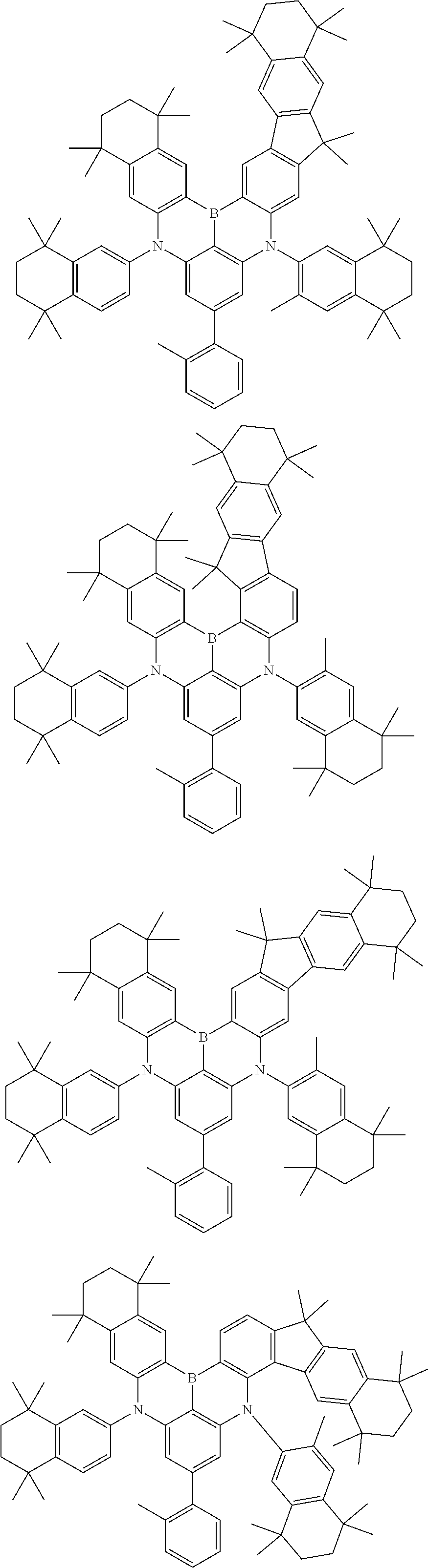

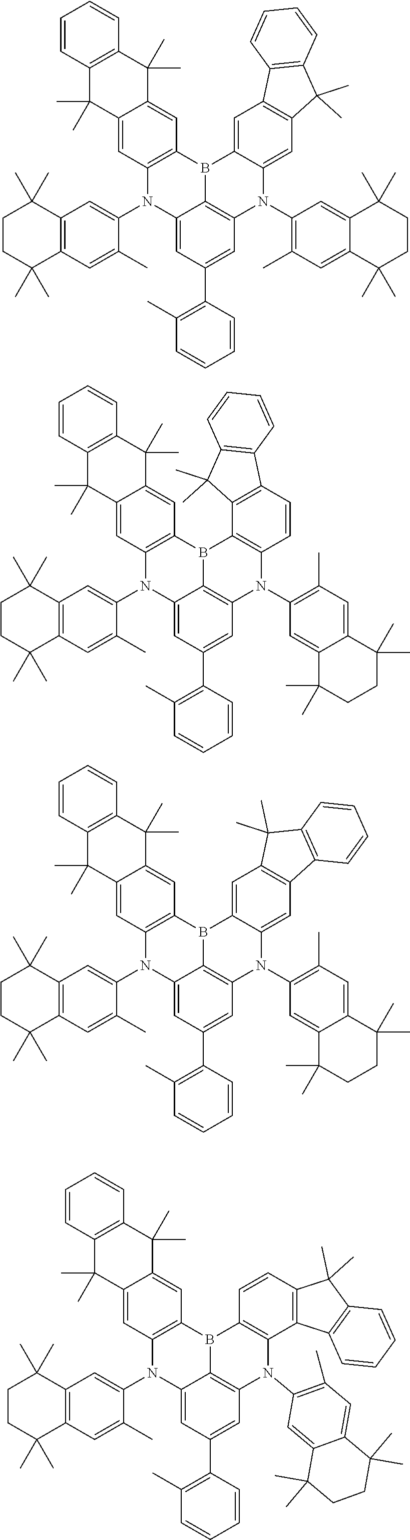

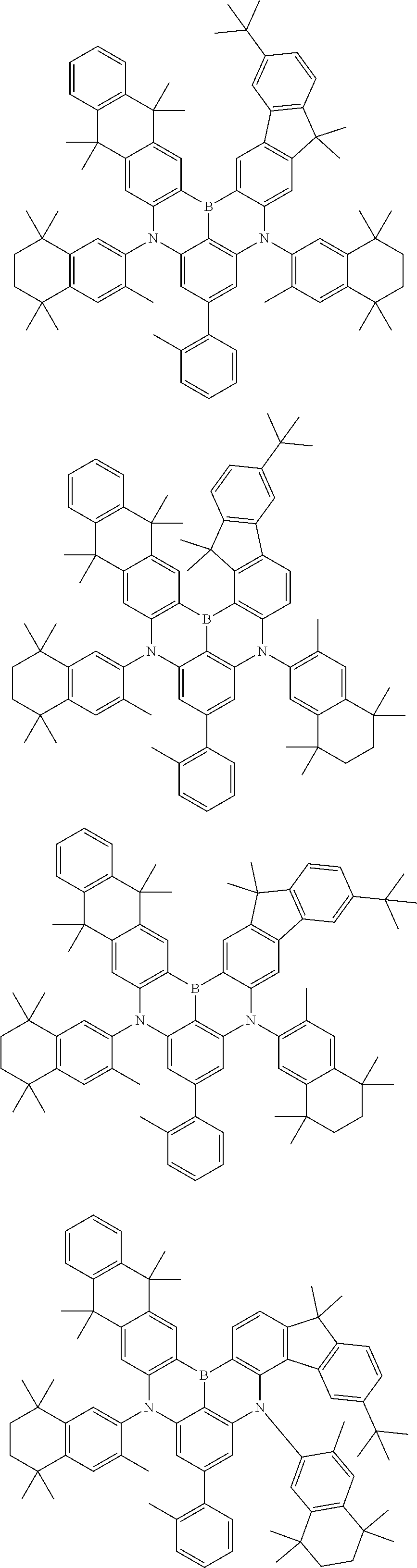

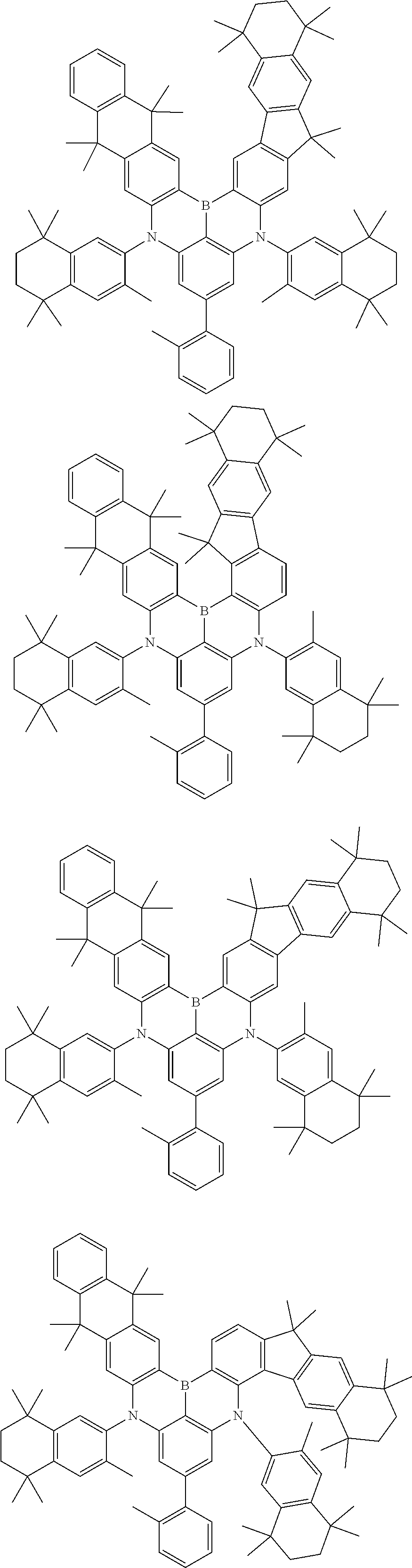

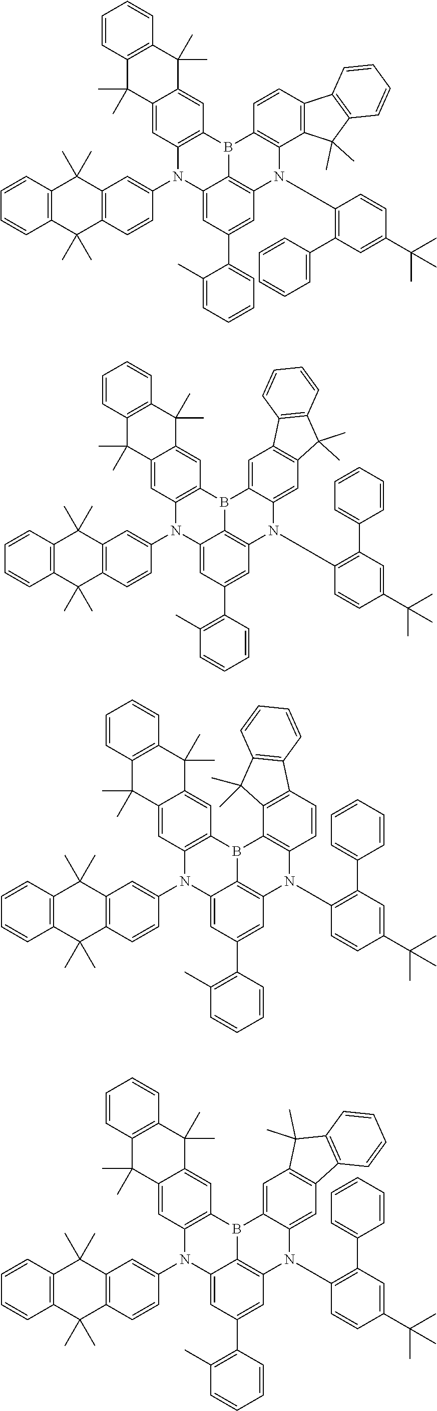

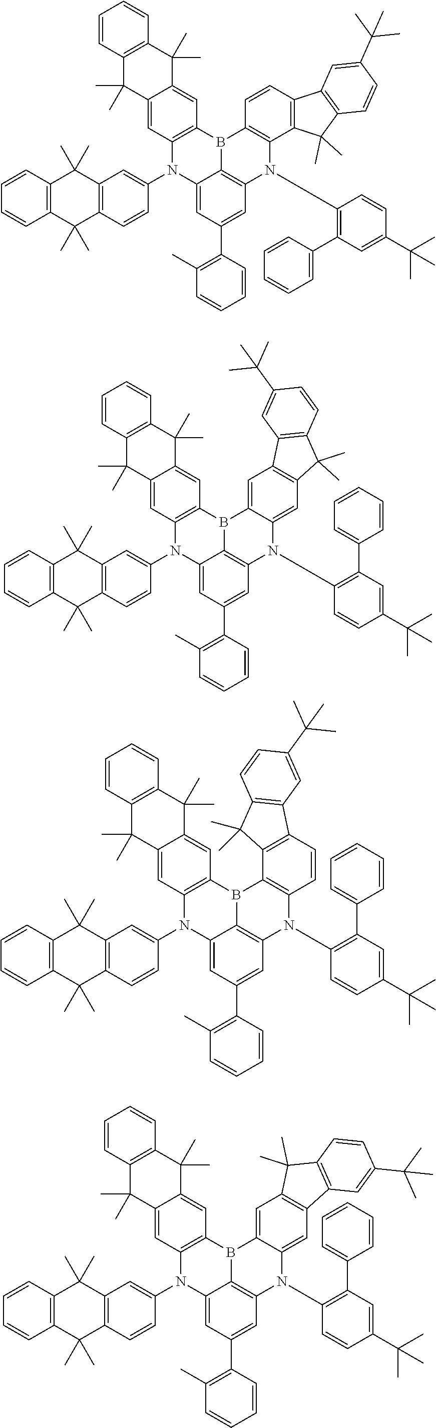

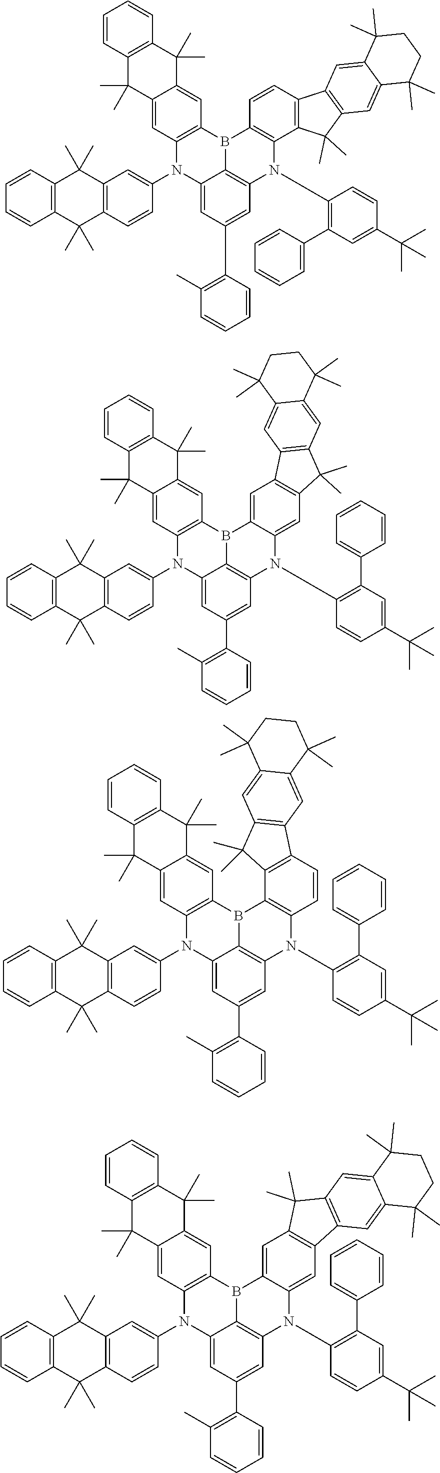

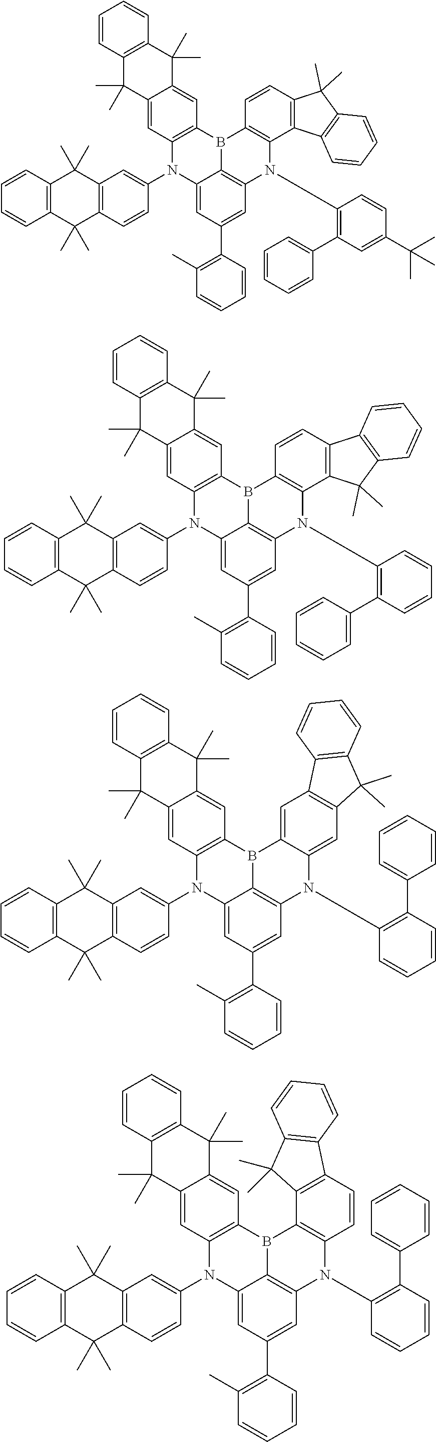

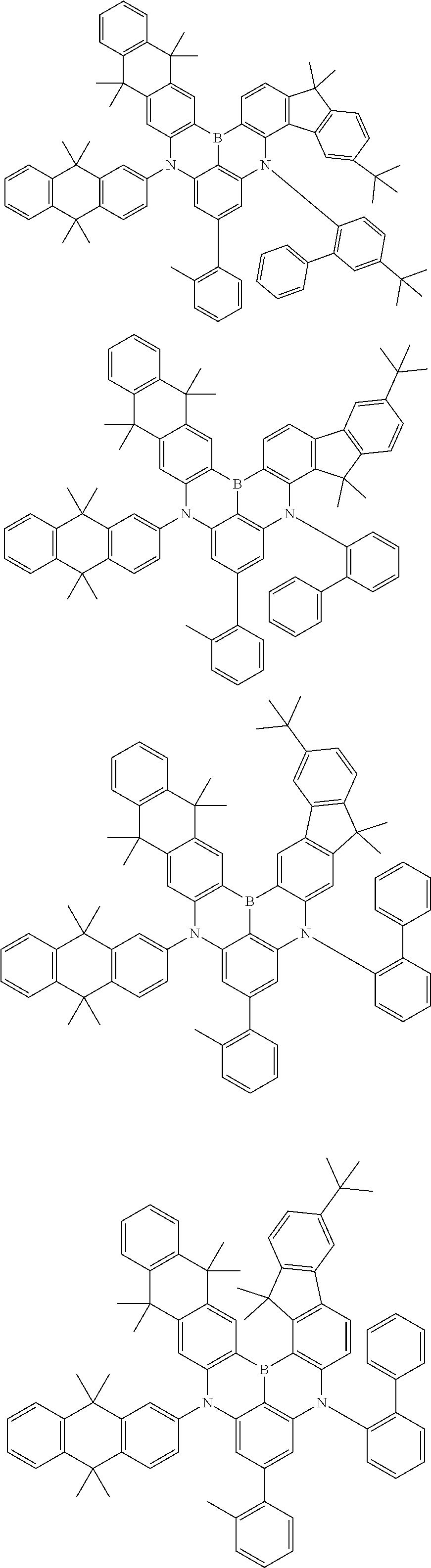

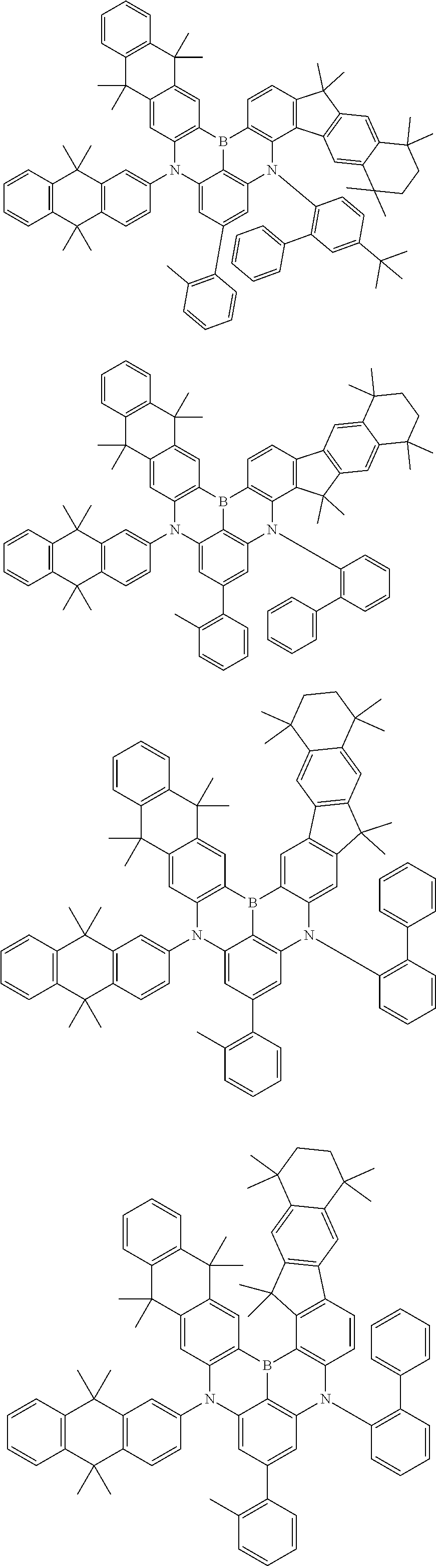

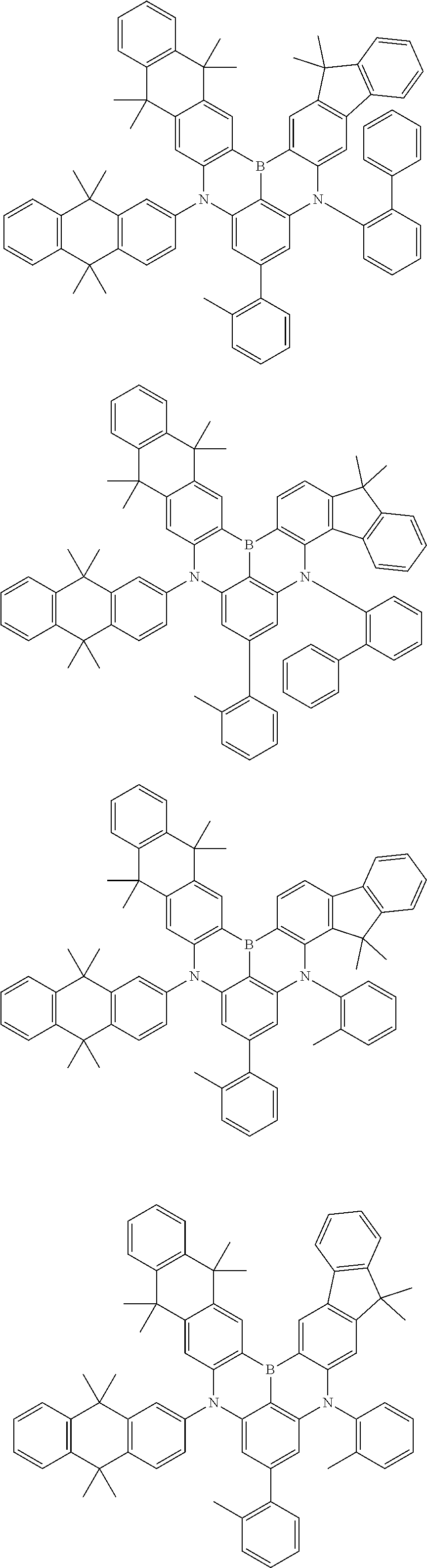

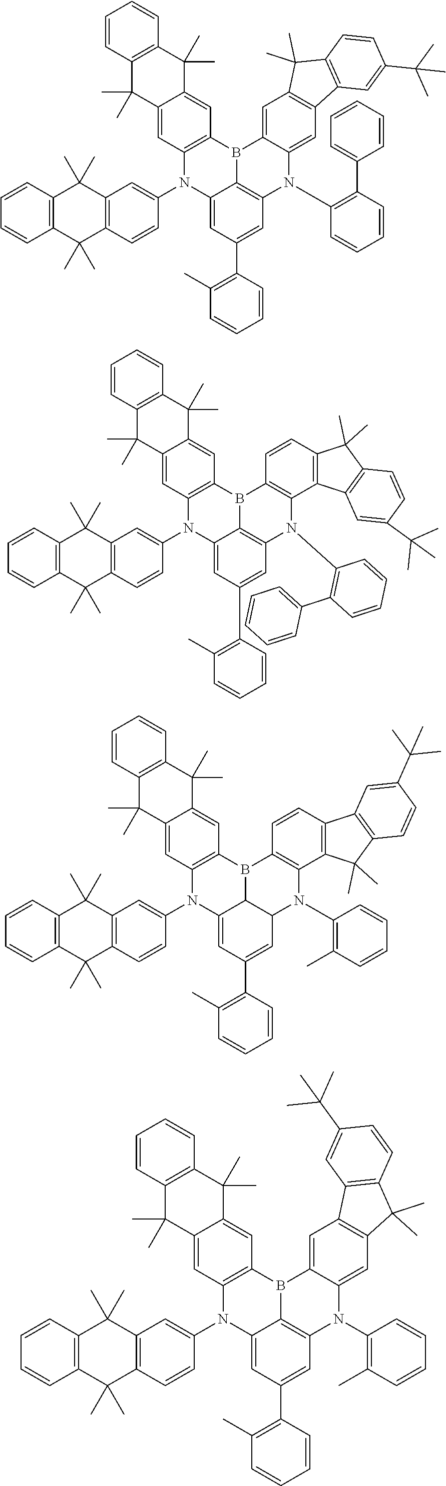

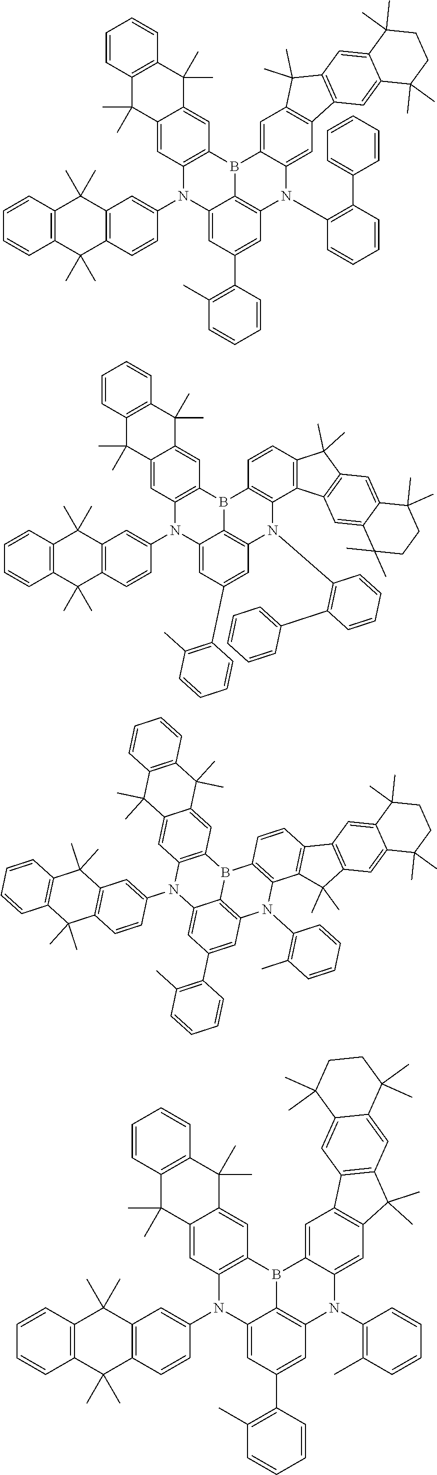

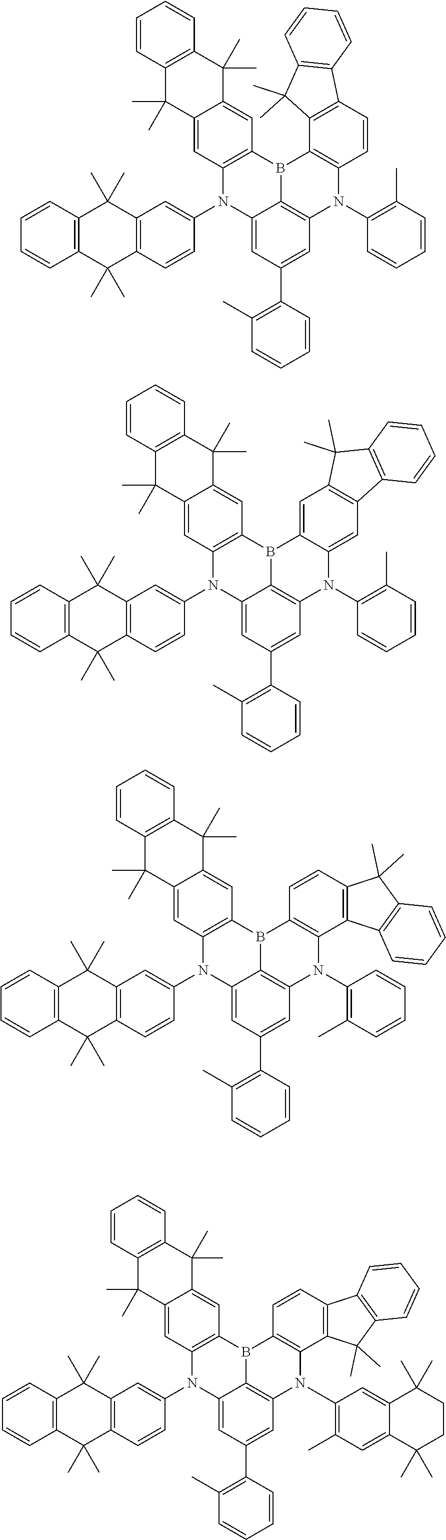

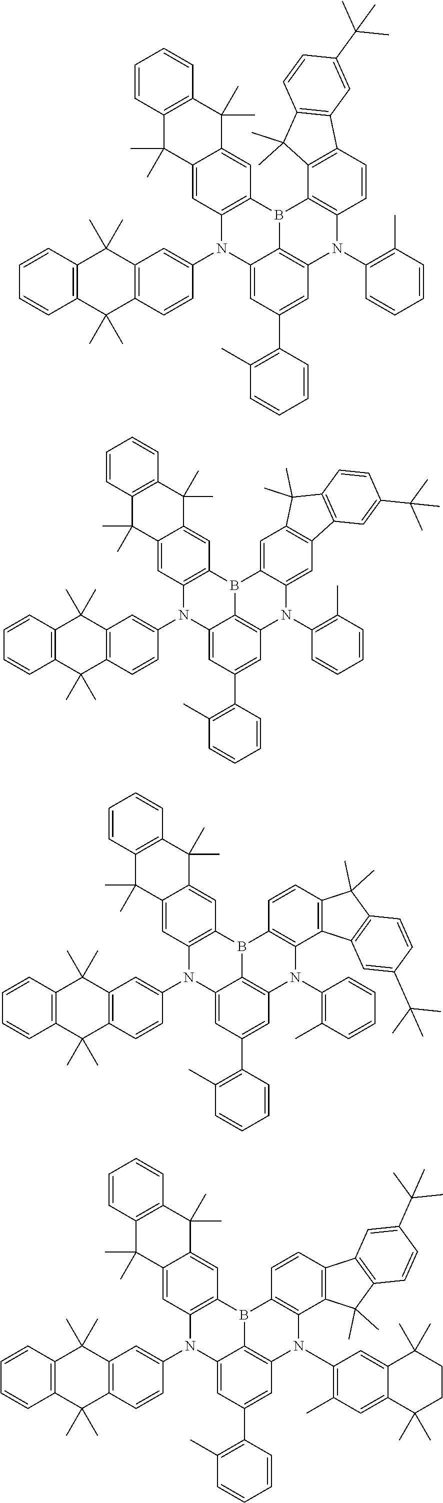

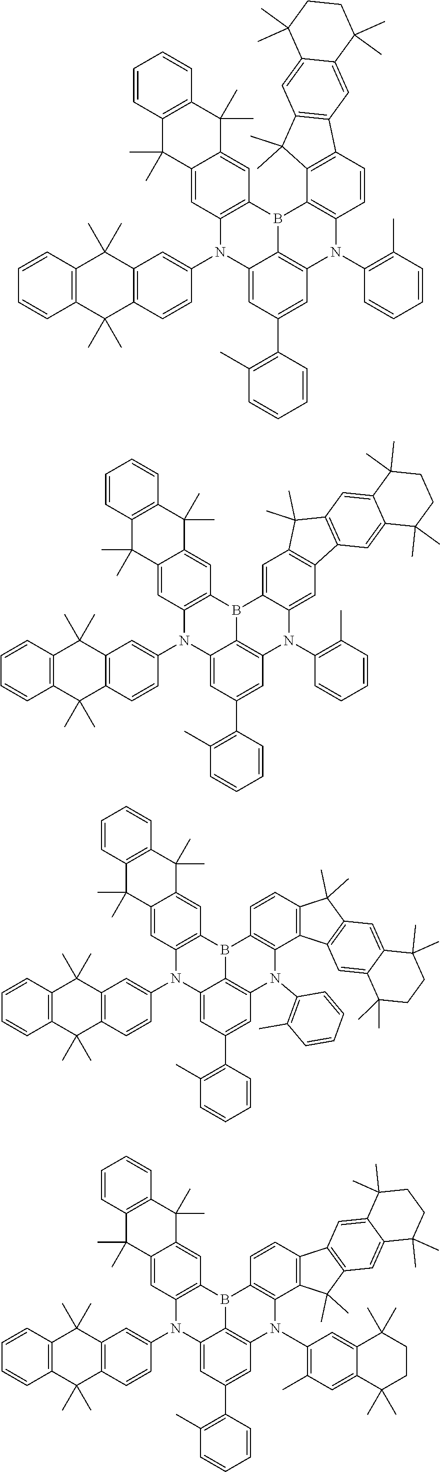

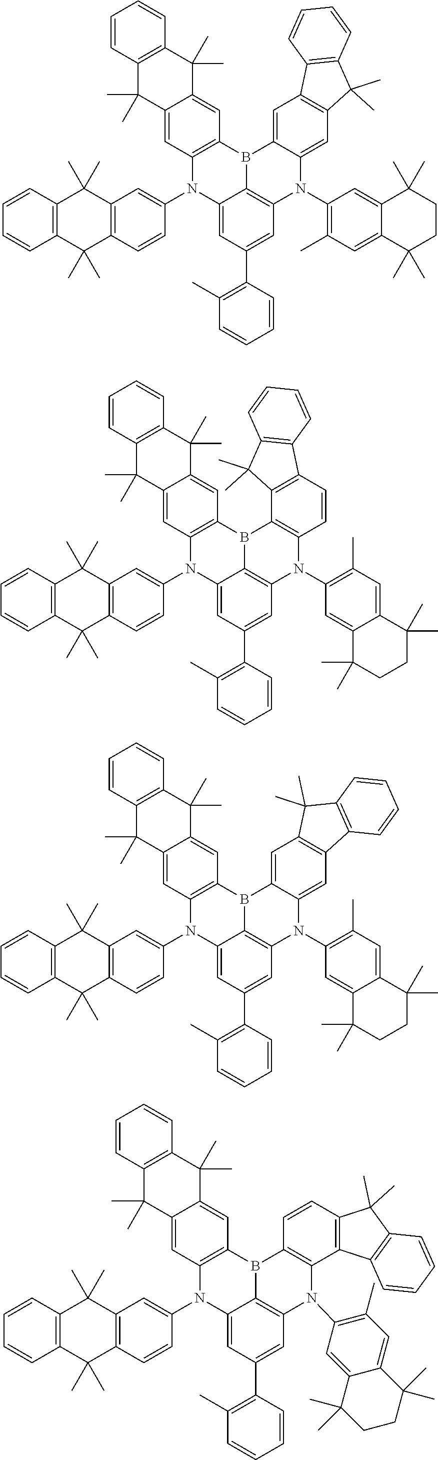

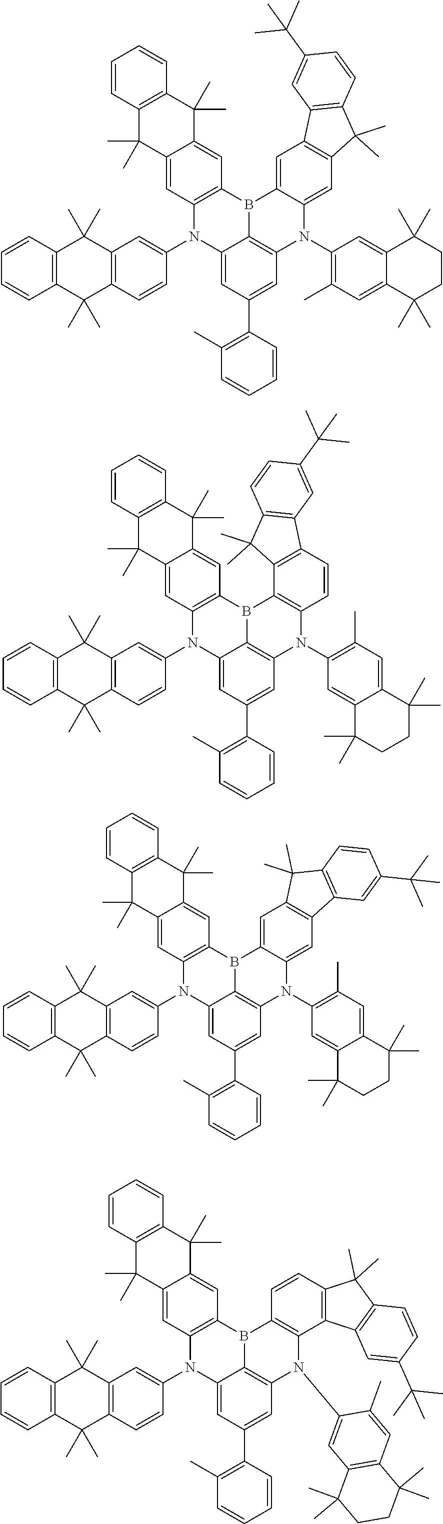

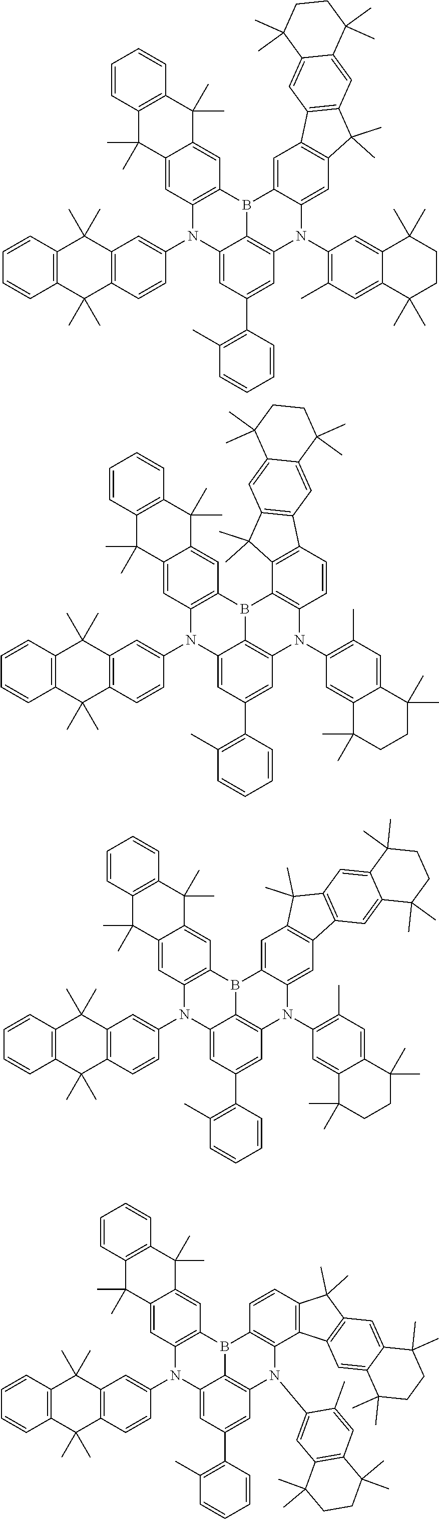

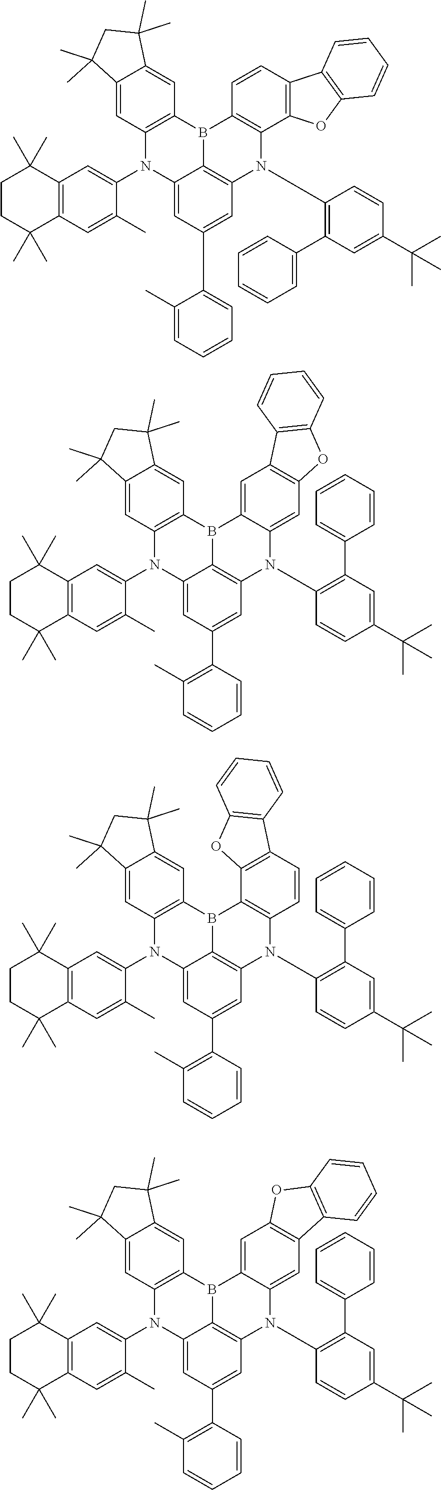

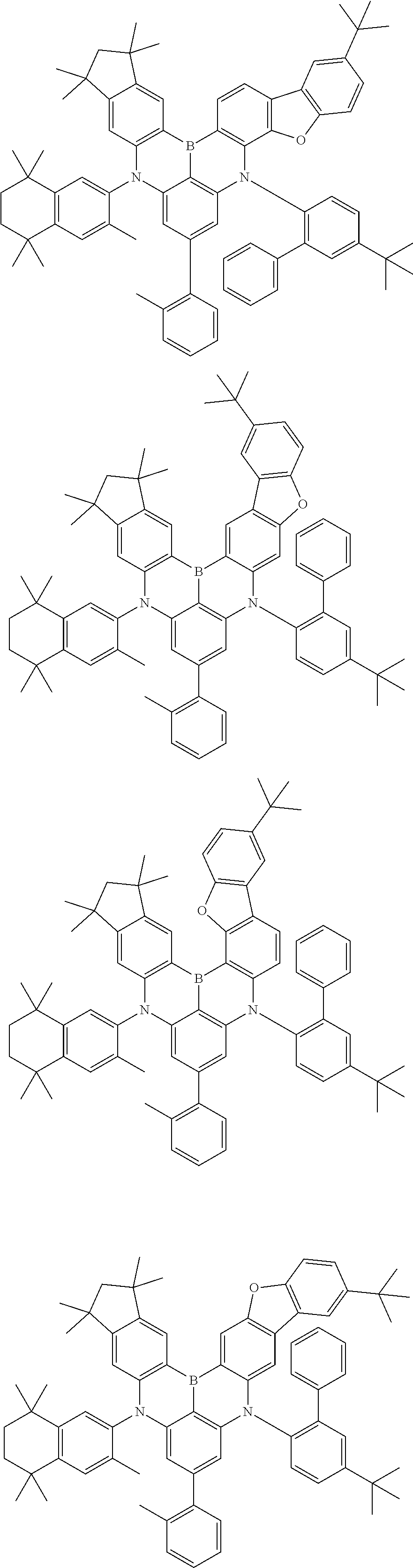

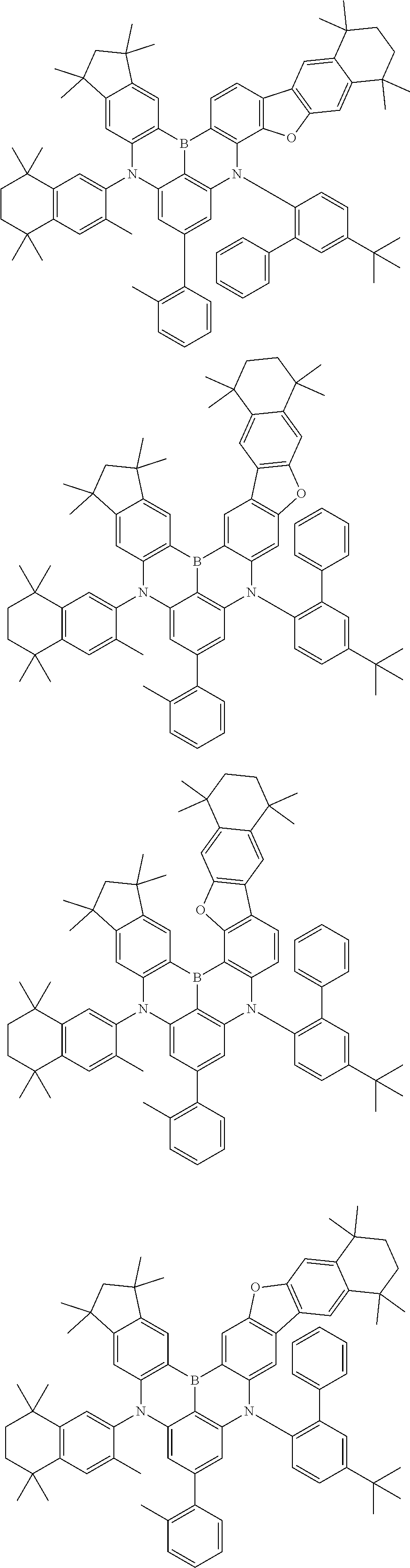

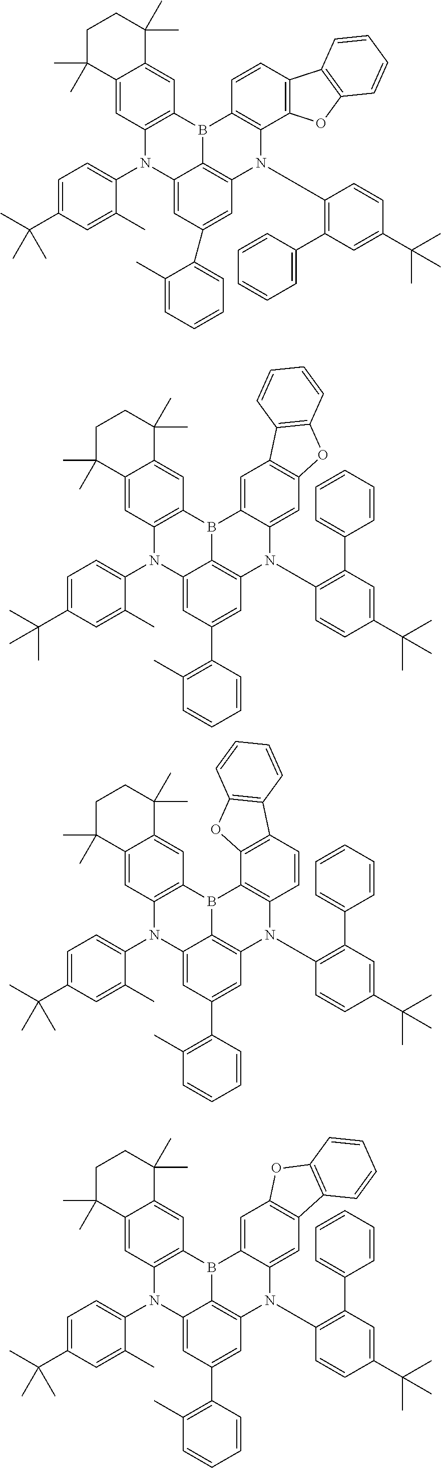

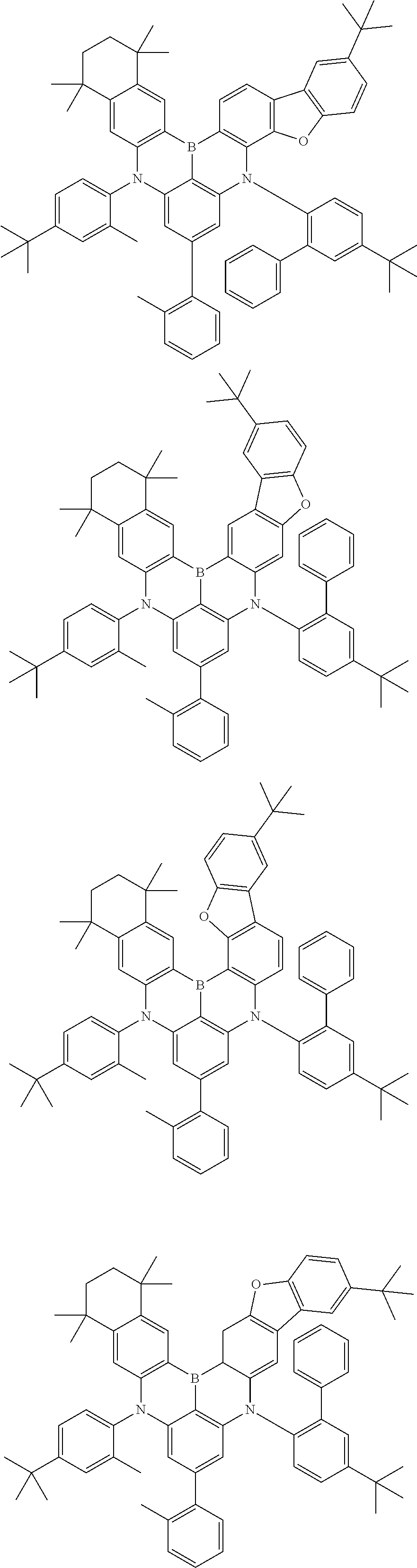

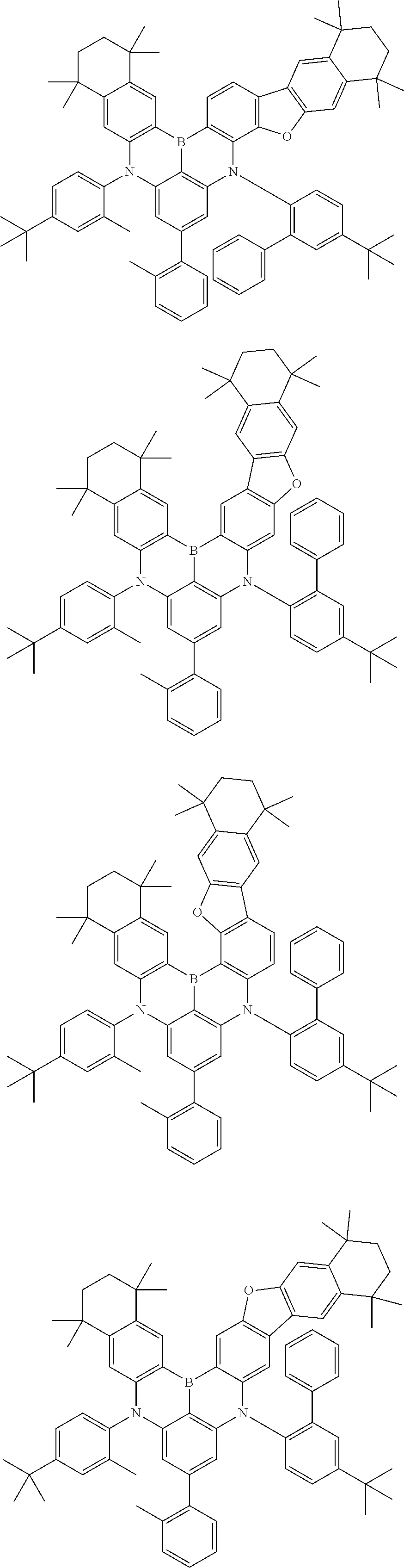

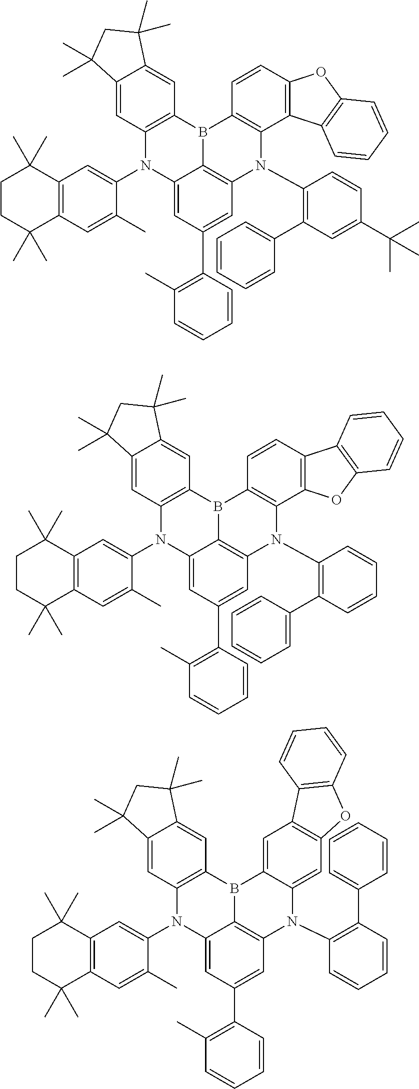 [SMILES: Cc1ccccc1-c1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1c(ccc4c1oc1ccccc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4oc5ccccc5c4cc1B3c1cc3c(cc1N2c1cc2c(cc1C)C(C)(C)CCC2(C)C)C(C)(C)CC3(C)C]

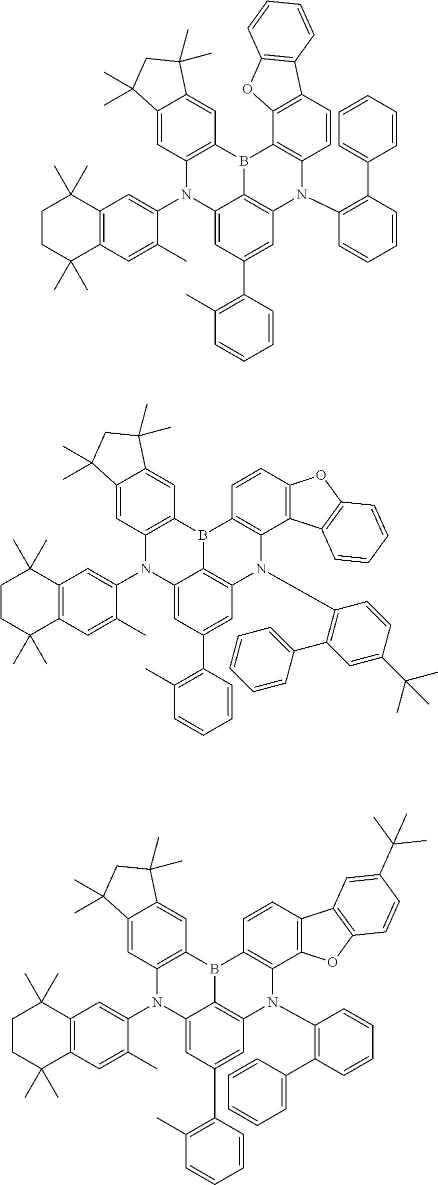 [SMILES: Cc1ccccc1-c1cc2c3c(c1)N(c1ccccc1-c1ccccc1)c1ccc4c(oc5ccccc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)CC3(C)C]

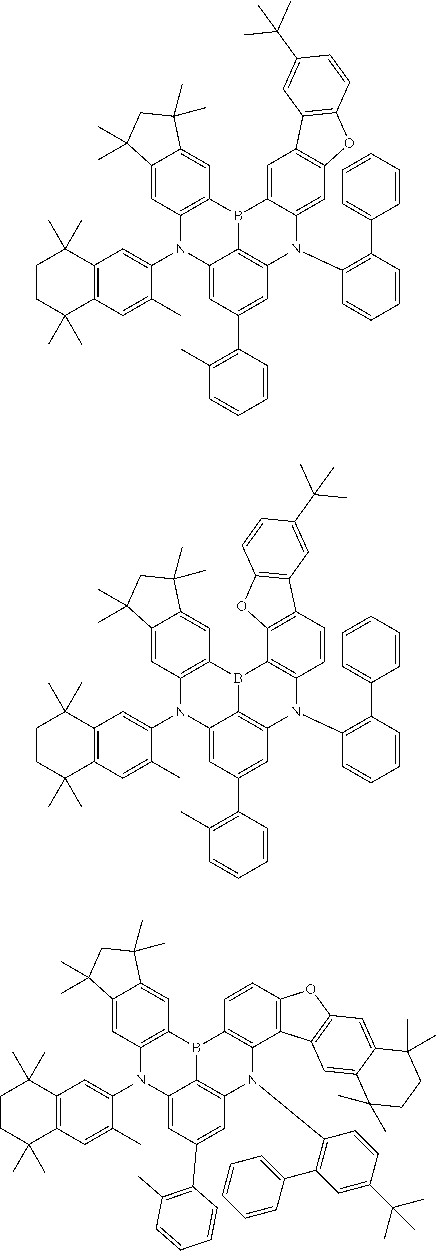 [SMILES: Cc1ccccc1-c1cc2c3c(c1)N(c1ccccc1-c1ccccc1)c1cc4oc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1ccc4c(oc5ccc(C(C)(C)C)cc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)CC3(C)C]

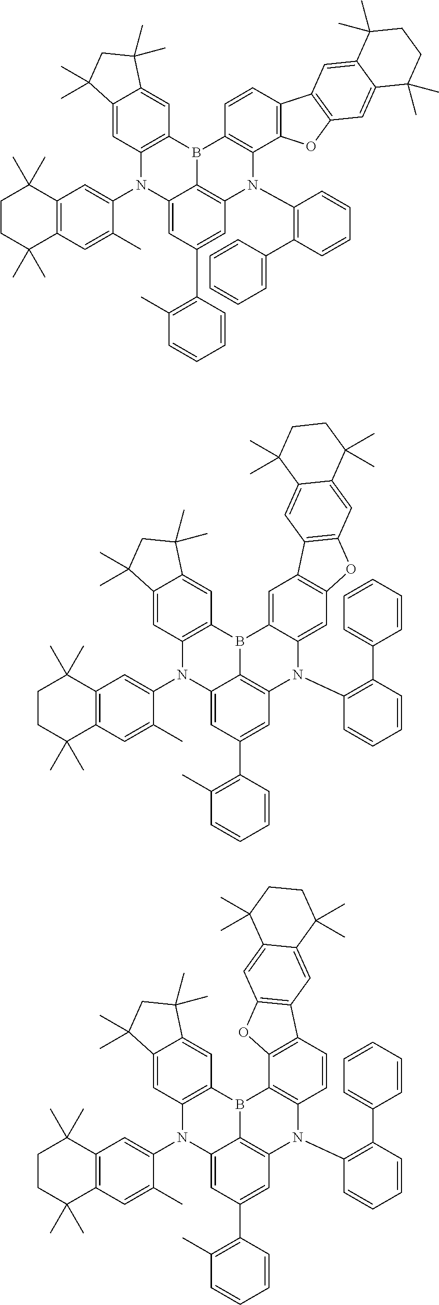 [SMILES: Cc1ccccc1-c1cc2c3c(c1)N(c1ccccc1-c1ccccc1)c1c(ccc4c1oc1cc5c(cc14)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4oc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1ccccc1-c1cc2c3c(c1)N(c1ccccc1-c1ccccc1)c1ccc4c(oc5cc6c(cc54)C(C)(C)CCC6(C)C)c1B3c1cc3c(cc1N2c1cc2c(cc1C)C(C)(C)CCC2(C)C)C(C)(C)CC3(C)C]

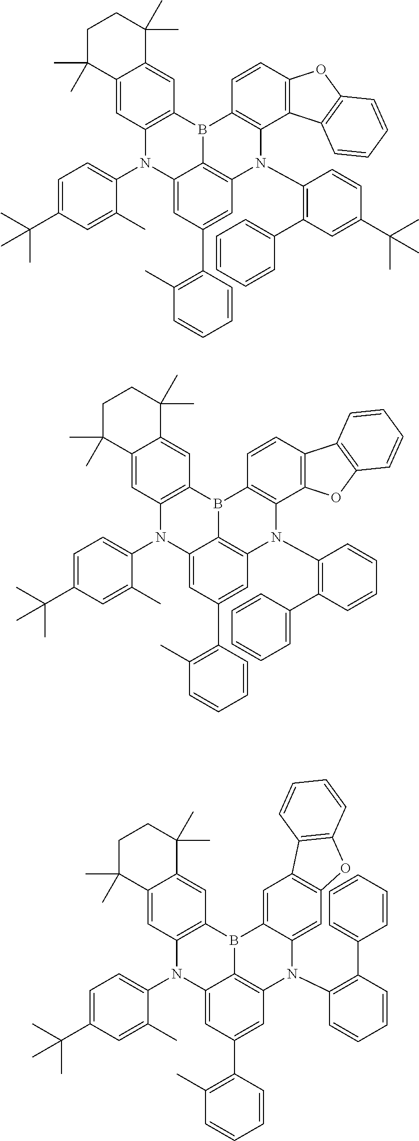

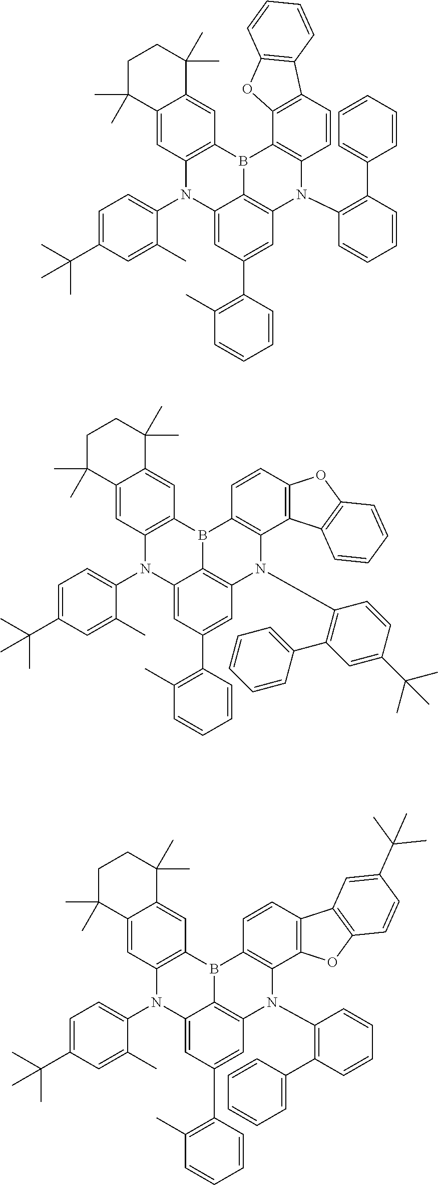

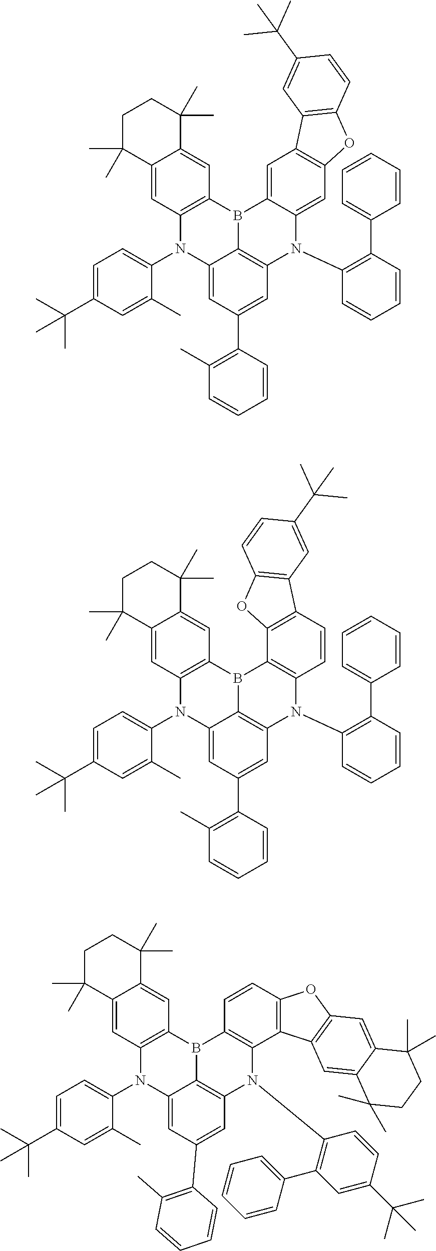 [SMILES: Cc1ccccc1-c1cc2c3c(c1)N(c1ccccc1-c1ccccc1)c1cc4oc5ccc(C(C)(C)C)cc5c4cc1B3c1cc3c(cc1N2c1ccc(C(C)(C)C)cc1C)C(C)(C)CCC3(C)C ; Cc1ccccc1-c1cc2c3c(c1)N(c1ccccc1-c1ccccc1)c1ccc4c(oc5ccc(C(C)(C)C)cc54)c1B3c1cc3c(cc1N2c1ccc(C(C)(C)C)cc1C)C(C)(C)CCC3(C)C ; Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc(C(C)(C)C)cc1C)C(C)(C)CCC3(C)C]

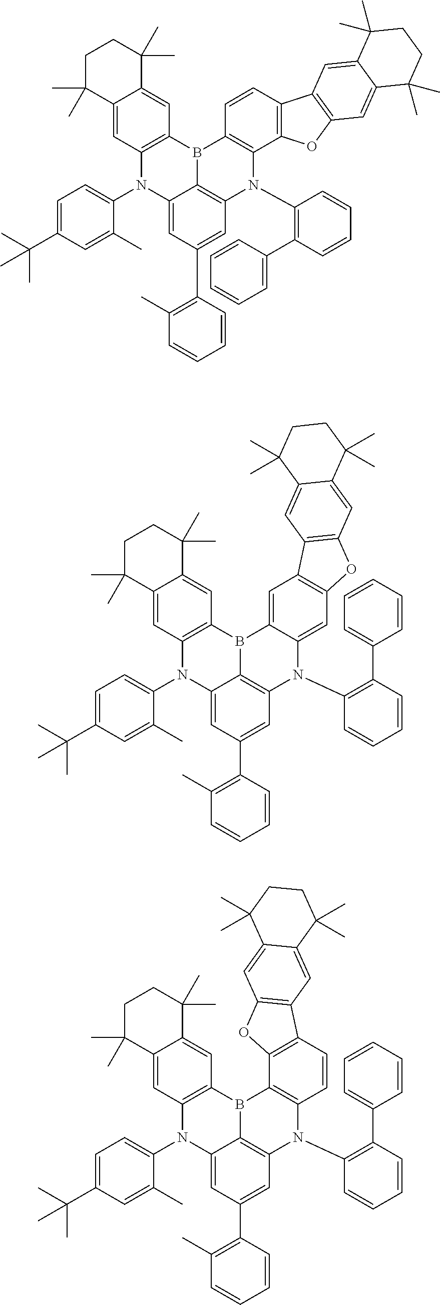

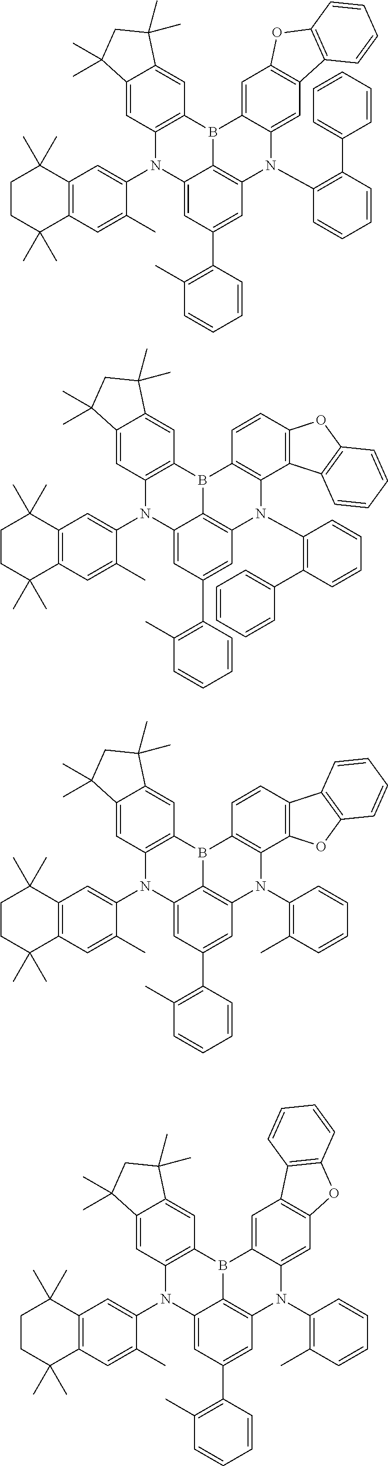 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)oc1ccccc14 ; Cc1ccccc1-c1cc2c3c(c1)N(c1ccccc1-c1ccccc1)c1c(ccc4oc5ccccc5c14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1c(ccc4c1oc1ccccc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4oc5ccccc5c4cc1B3c1cc3c(cc1N2c1cc2c(cc1C)C(C)(C)CCC2(C)C)C(C)(C)CC3(C)C]

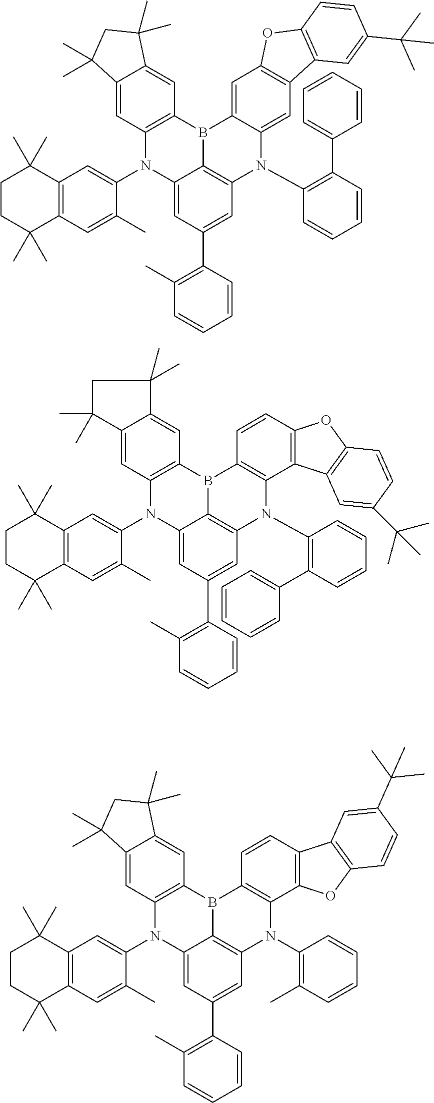

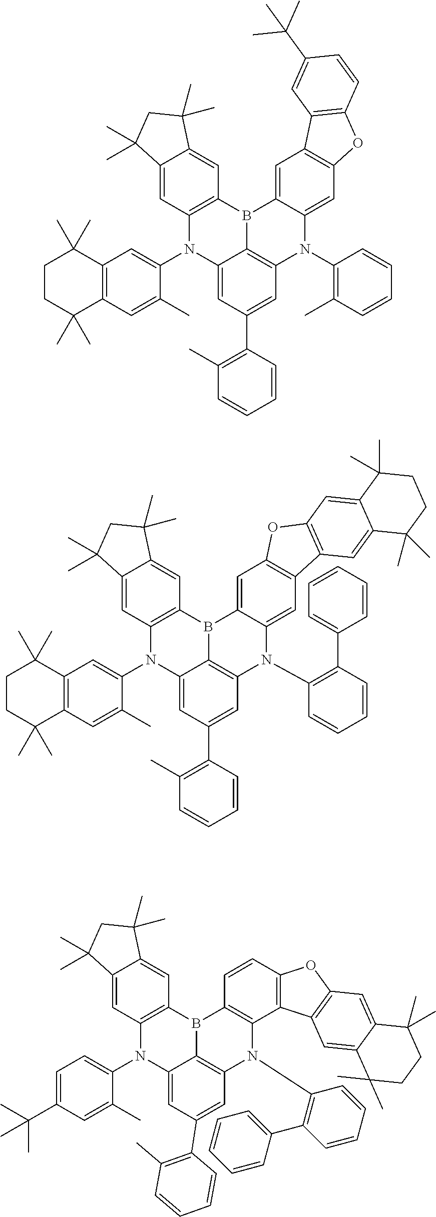

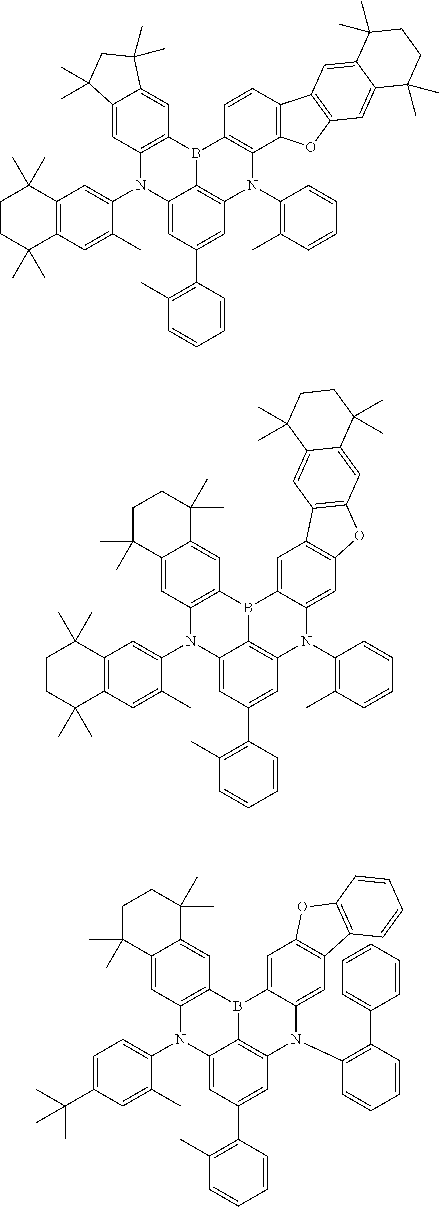

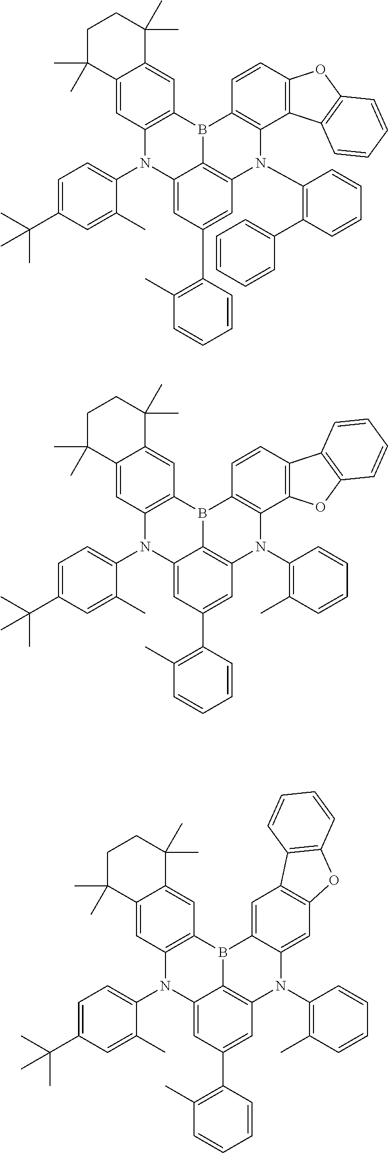 [SMILES: Cc1ccccc1-c1cc2c3c(c1)N(c1ccccc1-c1ccccc1)c1c(ccc4oc5ccccc5c14)B3c1cc3c(cc1N2c1ccc(C(C)(C)C)cc1C)C(C)(C)CCC3(C)C ; Cc1ccccc1-c1cc2c3c(c1)N(c1ccccc1C)c1c(ccc4c1oc1ccccc14)B3c1cc3c(cc1N2c1ccc(C(C)(C)C)cc1C)C(C)(C)CCC3(C)C ; Cc1ccccc1-c1cc2c3c(c1)N(c1ccccc1C)c1cc4oc5ccccc5c4cc1B3c1cc3c(cc1N2c1ccc(C(C)(C)C)cc1C)C(C)(C)CCC3(C)C]

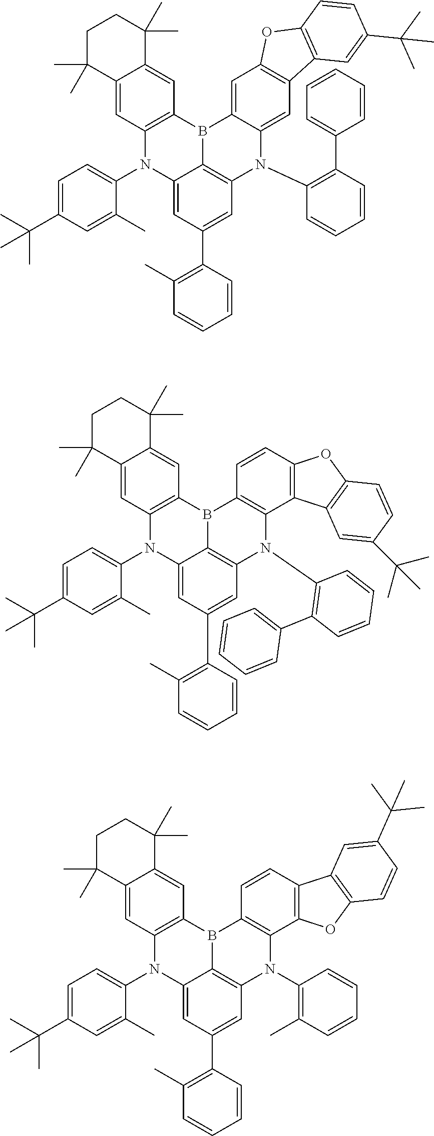

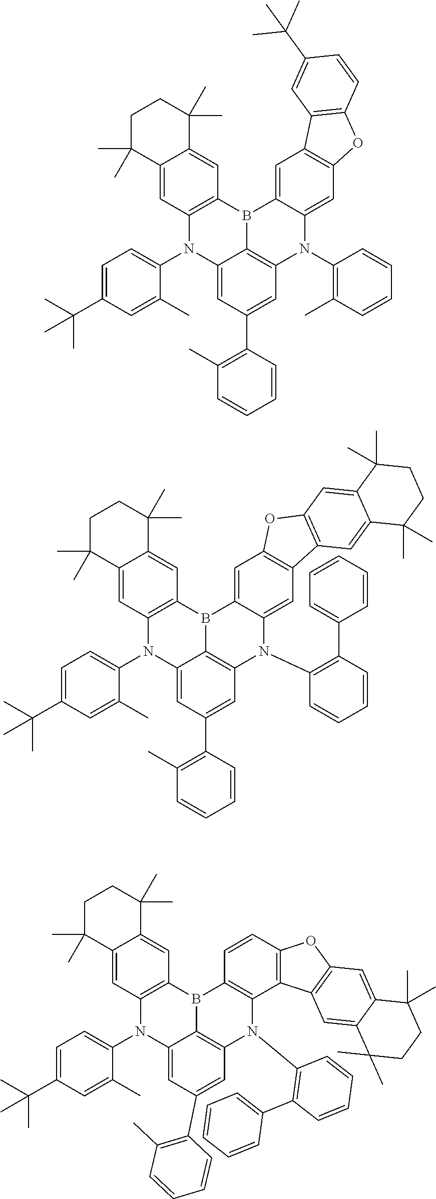

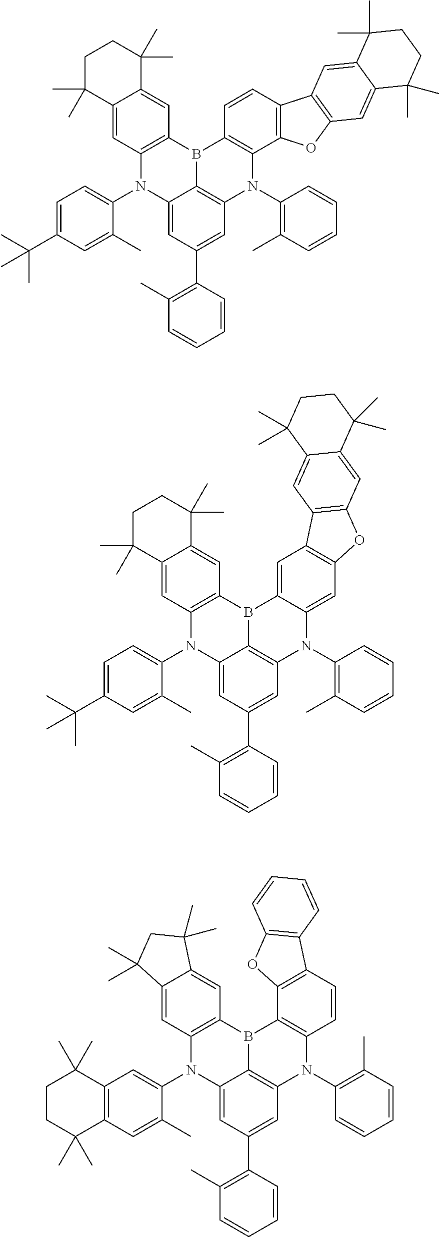

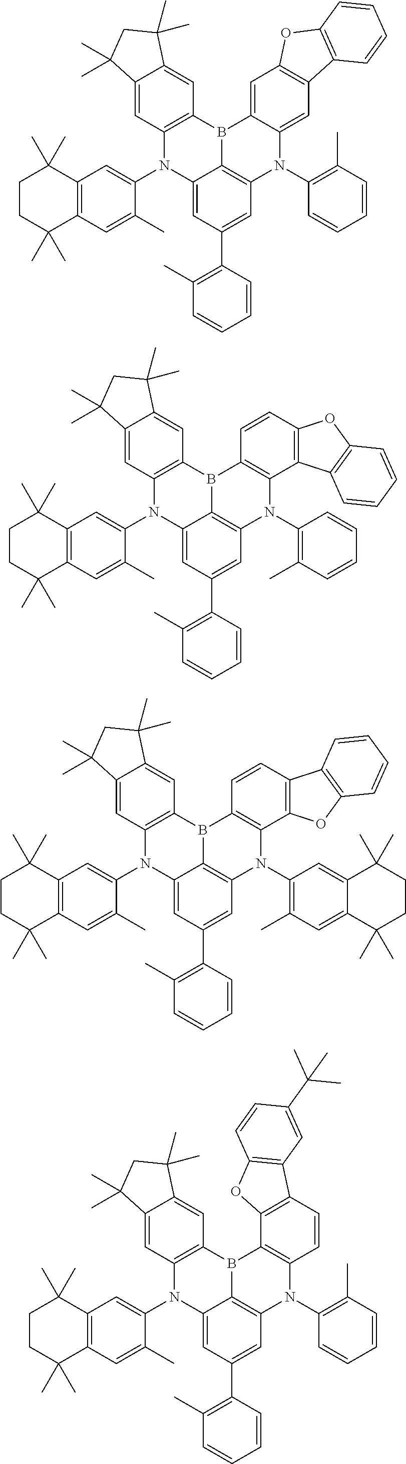 [SMILES: Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1ccccc14 ; Cc1ccccc1-c1cc2c3c(c1)N(c1ccccc1C)c1c(ccc4oc5ccccc5c14)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1ccc4c(oc5ccc(C(C)(C)C)cc54)c1B3c1cc3c(cc1N2c1cc2c(cc1C)C(C)(C)CCC2(C)C)C(C)(C)CC3(C)C]

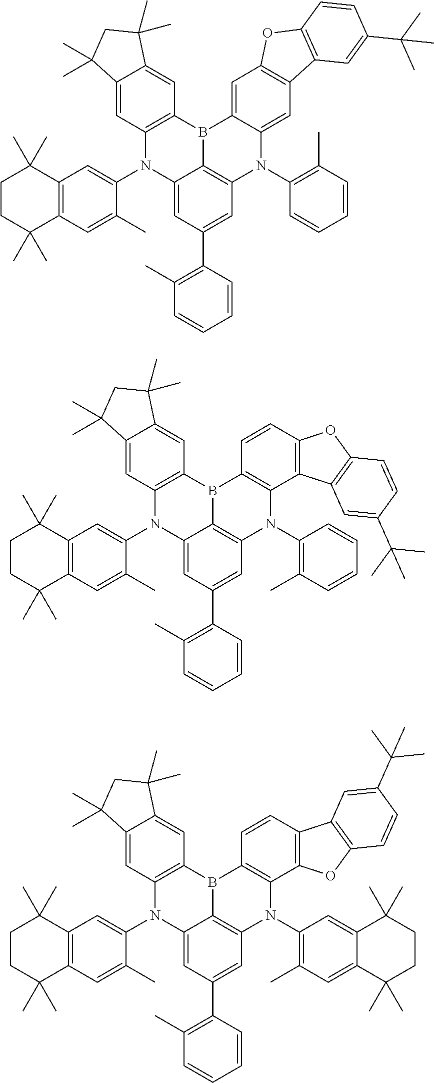 [SMILES: Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1ccc(C(C)(C)C)cc14 ; Cc1ccccc1-c1cc2c3c(c1)N(c1ccccc1C)c1c(ccc4oc5ccc(C(C)(C)C)cc5c14)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1c(ccc4c1oc1ccc(C(C)(C)C)cc14)B3c1cc3c(cc1N2c1cc2c(cc1C)C(C)(C)CCC2(C)C)C(C)(C)CC3(C)C]

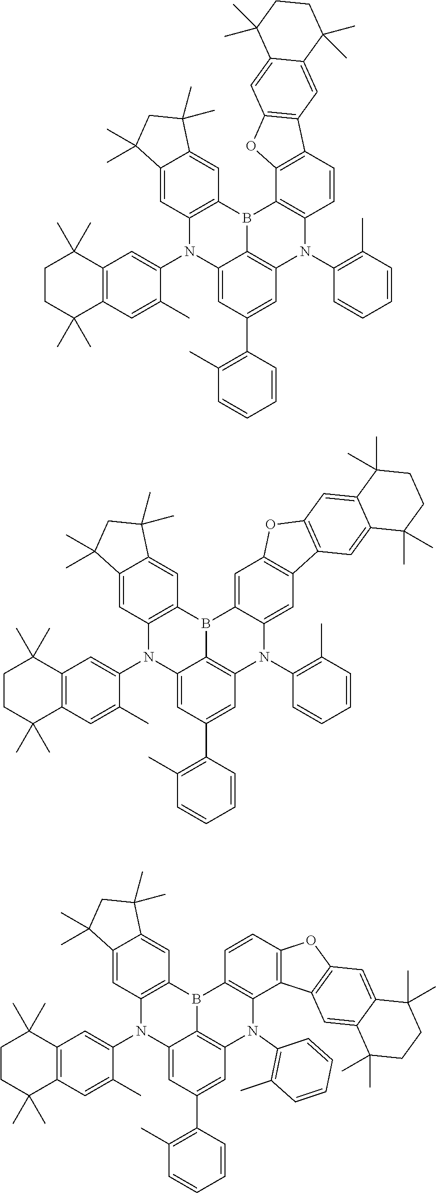 [SMILES: Cc1ccccc1-c1cc2c3c(c1)N(c1ccccc1C)c1ccc4c(oc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1cc2c(cc14)C(C)(C)CCC2(C)C ; Cc1ccccc1-c1cc2c3c(c1)N(c1ccccc1C)c1c(ccc4oc5cc6c(cc5c14)C(C)(C)CCC6(C)C)B3c1cc3c(cc1N2c1cc2c(cc1C)C(C)(C)CCC2(C)C)C(C)(C)CC3(C)C]

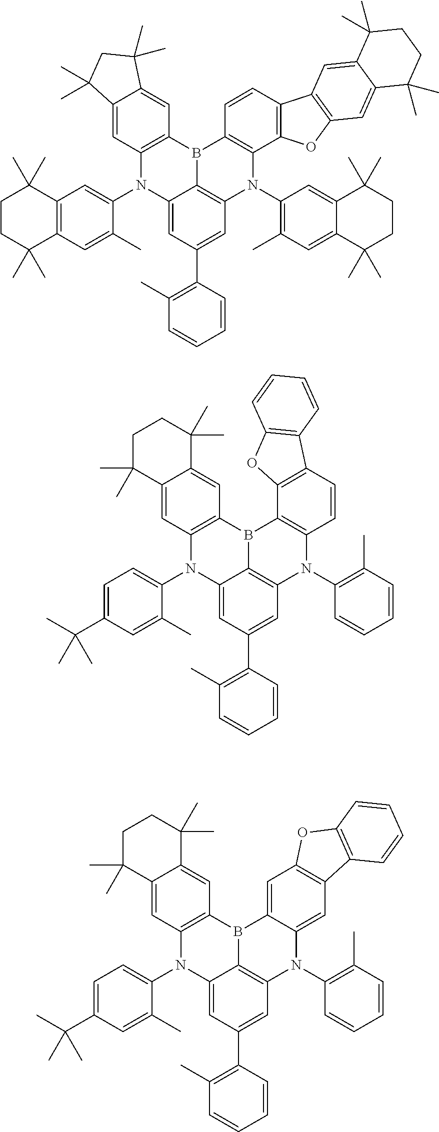

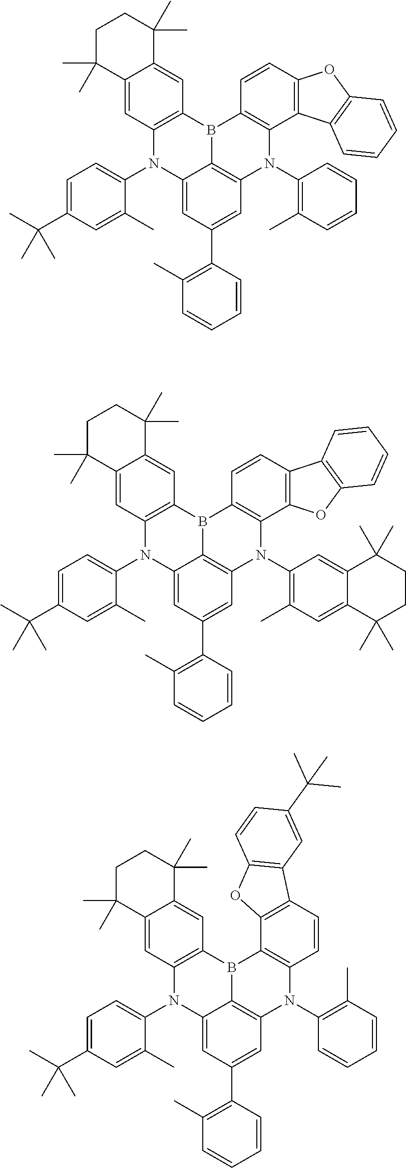 [SMILES: Cc1ccccc1-c1cc2c3c(c1)N(c1ccccc1C)c1c(ccc4oc5ccccc5c14)B3c1cc3c(cc1N2c1ccc(C(C)(C)C)cc1C)C(C)(C)CCC3(C)C ; Cc1ccccc1-c1cc2c3c(c1)N(c1cc4c(cc1C)C(C)(C)CCC4(C)C)c1c(ccc4c1oc1ccccc14)B3c1cc3c(cc1N2c1ccc(C(C)(C)C)cc1C)C(C)(C)CCC3(C)C ; Cc1ccccc1-c1cc2c3c(c1)N(c1ccccc1C)c1ccc4c(oc5ccc(C(C)(C)C)cc54)c1B3c1cc3c(cc1N2c1ccc(C(C)(C)C)cc1C)C(C)(C)CCC3(C)C]

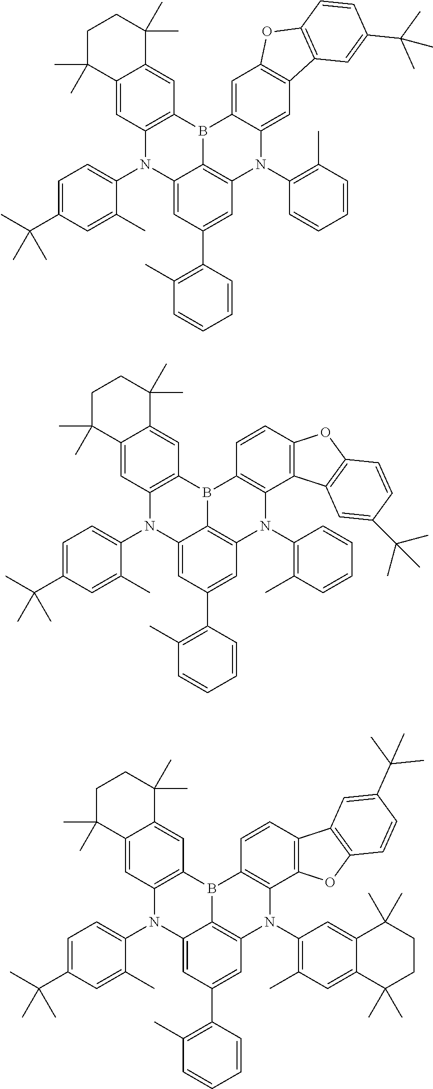

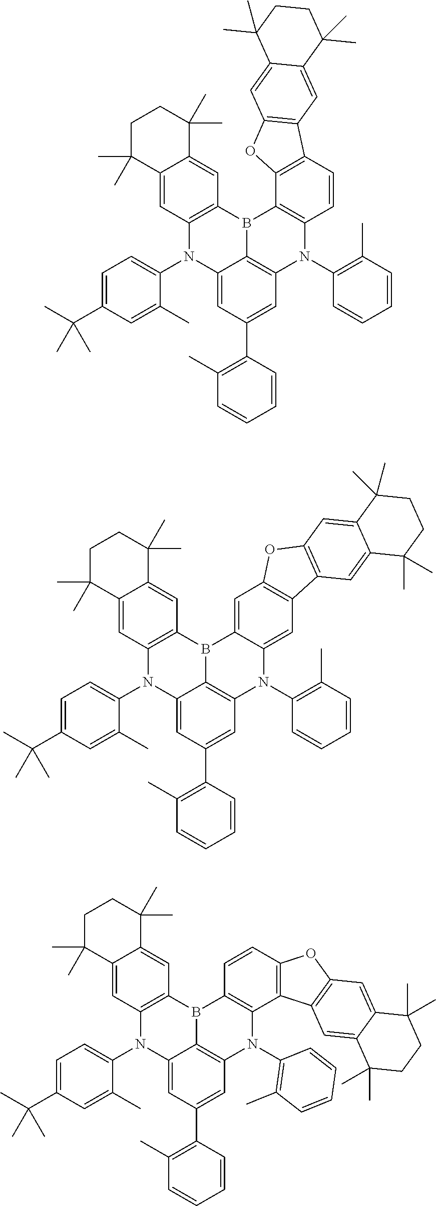

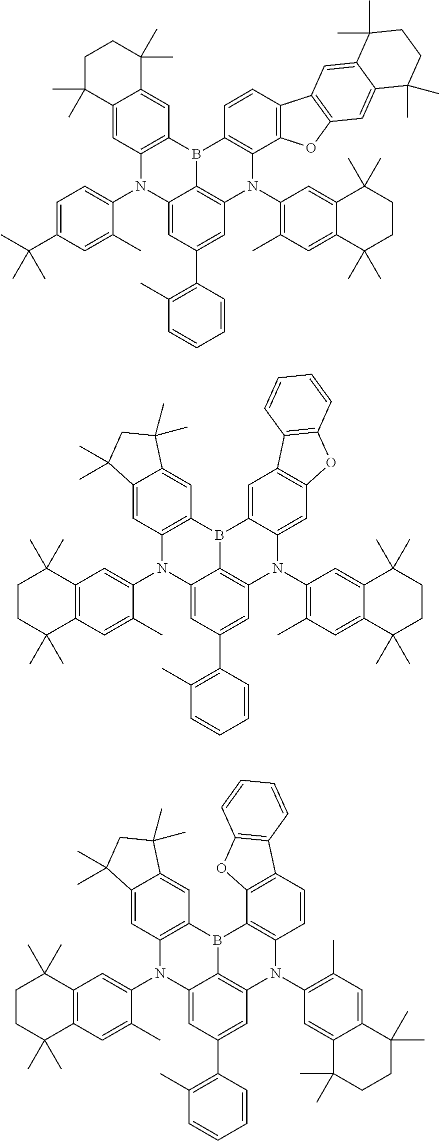 [SMILES: Cc1ccccc1-c1cc2c3c(c1)N(c1cc4c(cc1C)C(C)(C)CCC4(C)C)c1c(ccc4c1oc1cc5c(cc14)C(C)(C)CCC5(C)C)B3c1cc3c(cc1N2c1ccc(C(C)(C)C)cc1C)C(C)(C)CCC3(C)C ; Cc1ccccc1-c1cc2c3c(c1)N(c1cc4c(cc1C)C(C)(C)CCC4(C)C)c1cc4oc5ccccc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1ccc4c(oc5ccccc54)c1B3c1cc3c(cc1N2c1cc2c(cc1C)C(C)(C)CCC2(C)C)C(C)(C)CC3(C)C]

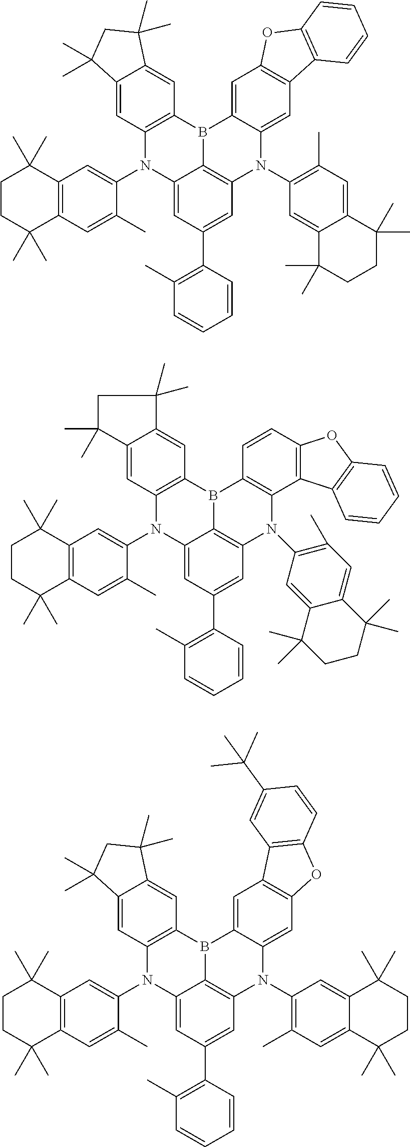

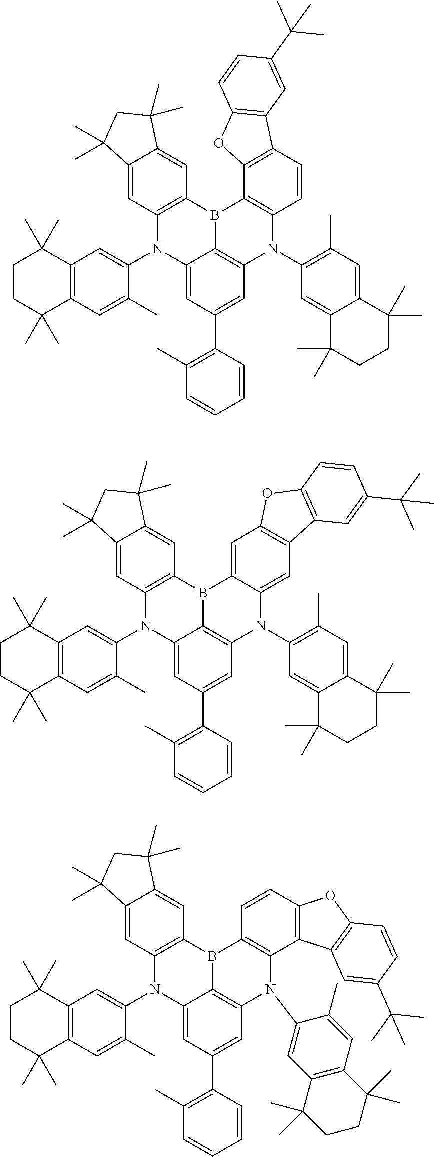 [SMILES: Cc1ccccc1-c1cc2c3c(c1)N(c1cc4c(cc1C)C(C)(C)CCC4(C)C)c1ccc4c(oc5ccc(C(C)(C)C)cc54)c1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)oc1ccc(C(C)(C)C)cc14 ; Cc1ccccc1-c1cc2c3c(c1)N(c1cc4c(cc1C)C(C)(C)CCC4(C)C)c1c(ccc4oc5ccc(C(C)(C)C)cc5c14)B3c1cc3c(cc1N2c1cc2c(cc1C)C(C)(C)CCC2(C)C)C(C)(C)CC3(C)C]

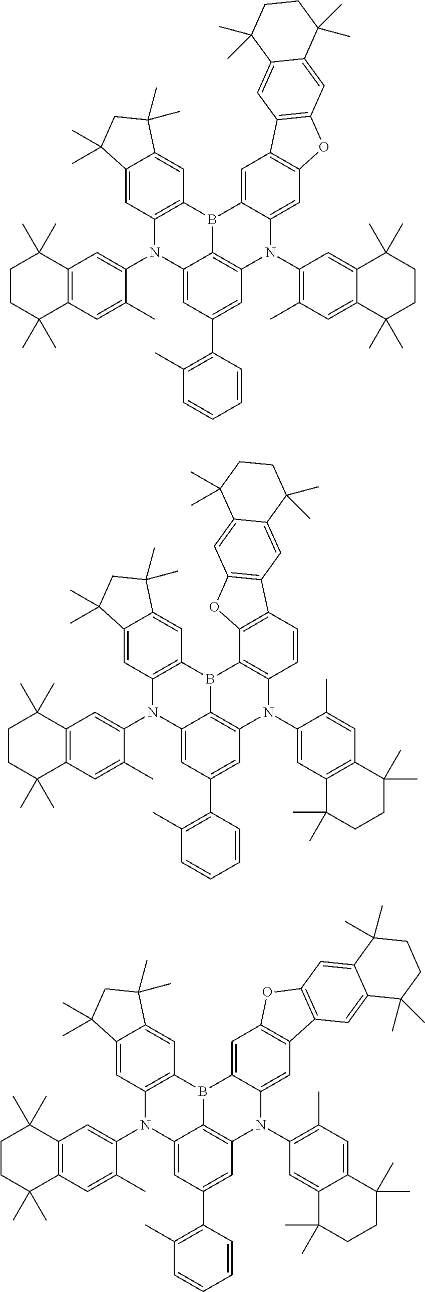 [SMILES: Cc1ccccc1-c1cc2c3c(c1)N(c1cc4c(cc1C)C(C)(C)CCC4(C)C)c1cc4oc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1ccccc1-c1cc2c3c(c1)N(c1cc4c(cc1C)C(C)(C)CCC4(C)C)c1ccc4c(oc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)oc1cc2c(cc14)C(C)(C)CCC2(C)C]

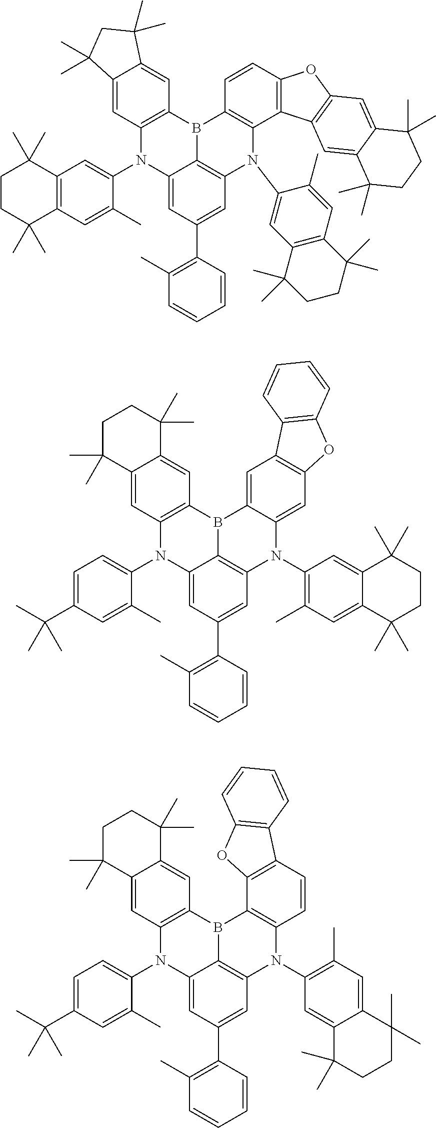

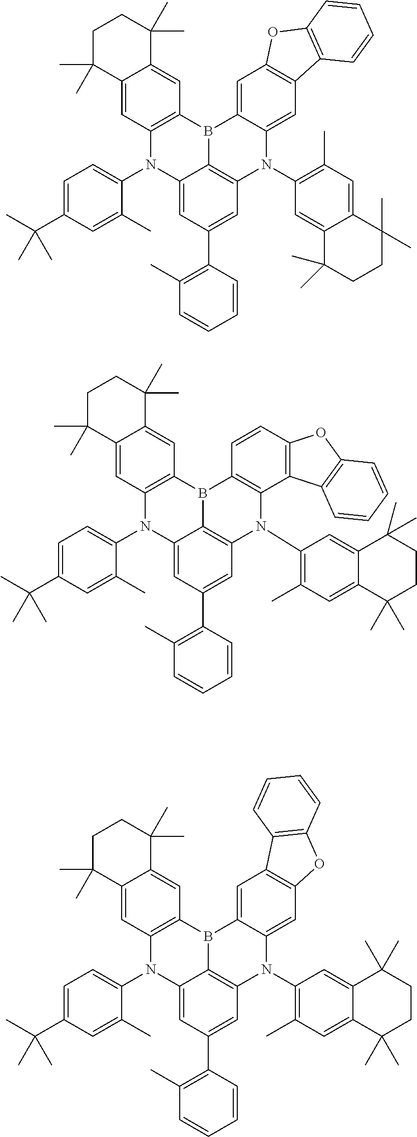

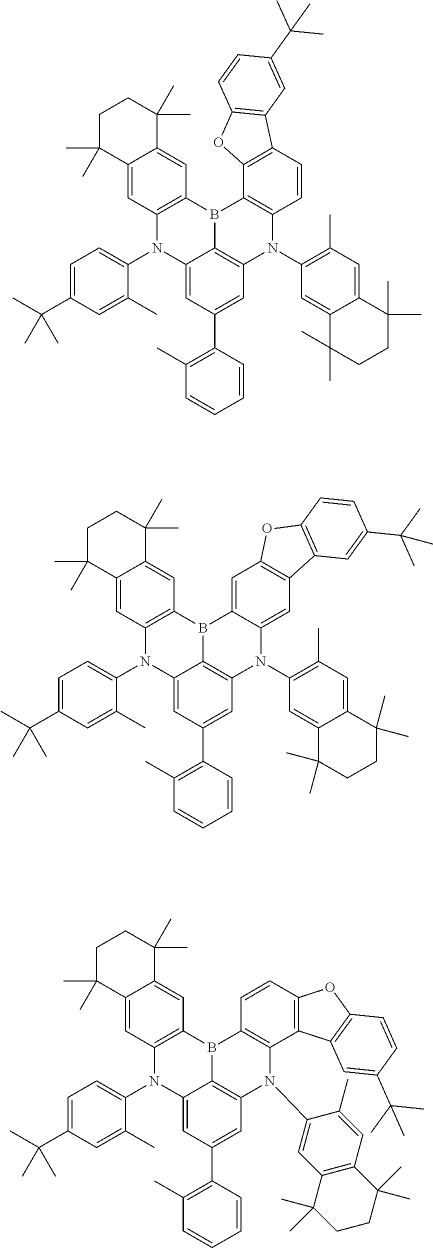

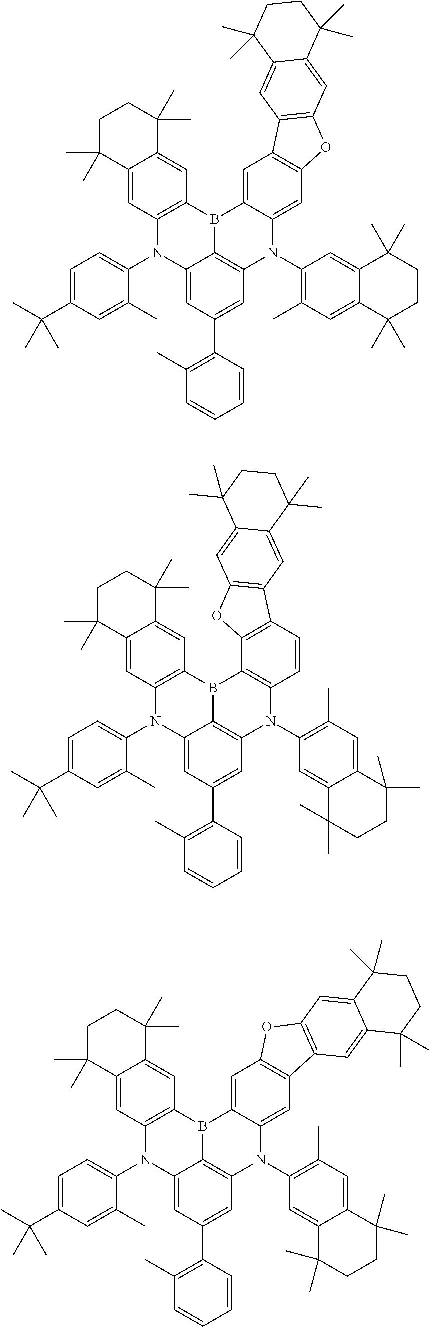

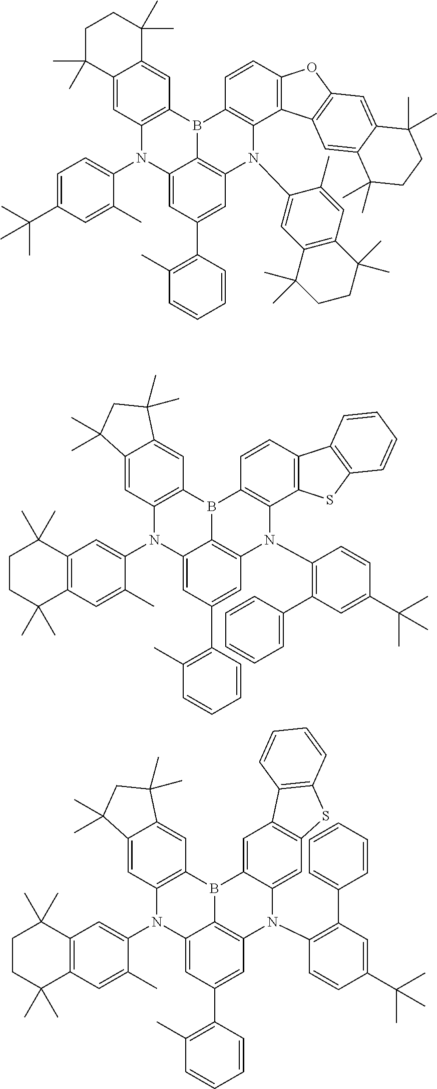 [SMILES: Cc1ccccc1-c1cc2c3c(c1)N(c1cc4c(cc1C)C(C)(C)CCC4(C)C)c1c(ccc4oc5cc6c(cc5c14)C(C)(C)CCC6(C)C)B3c1cc3c(cc1N2c1ccc(C(C)(C)C)cc1C)C(C)(C)CCC3(C)C ; Cc1ccccc1-c1cc2c3c(c1)N(c1ccc(C(C)(C)C)cc1-c1ccccc1)c1c(ccc4c1sc1ccccc14)B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4sc5ccccc5c4cc1B3c1cc3c(cc1N2c1cc2c(cc1C)C(C)(C)CCC2(C)C)C(C)(C)CC3(C)C]

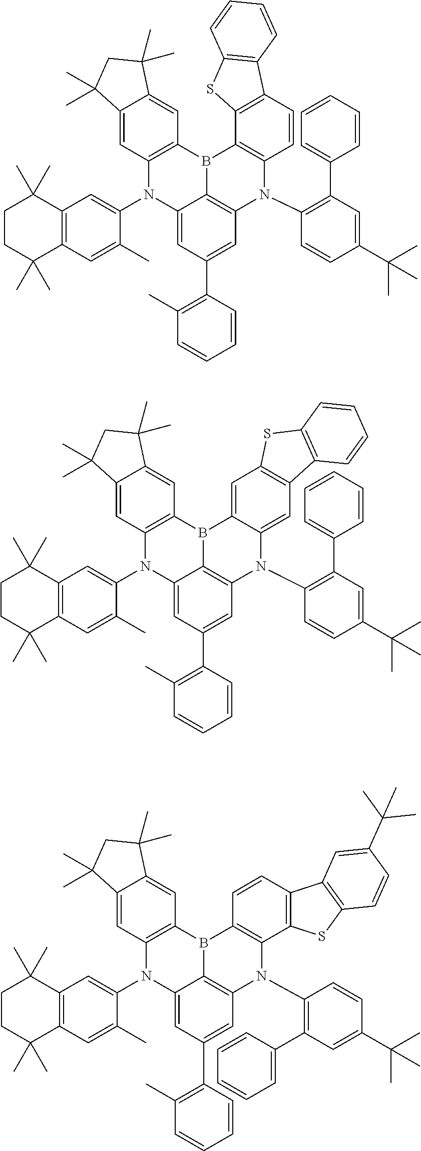 [SMILES: Cc1ccccc1-c1cc2c3c(c1)N(c1ccc(C(C)(C)C)cc1-c1ccccc1)c1ccc4c(sc5ccccc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)sc1ccccc14 ; Cc1ccccc1-c1cc2c3c(c1)N(c1ccc(C(C)(C)C)cc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)CC3(C)C]

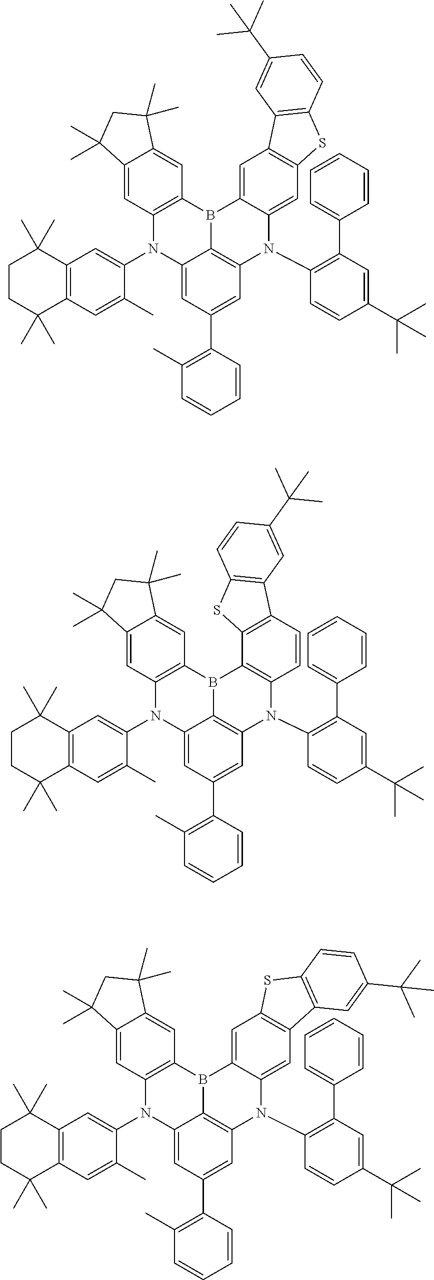 [SMILES: Cc1ccccc1-c1cc2c3c(c1)N(c1ccc(C(C)(C)C)cc1-c1ccccc1)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)sc1ccc(C(C)(C)C)cc14]

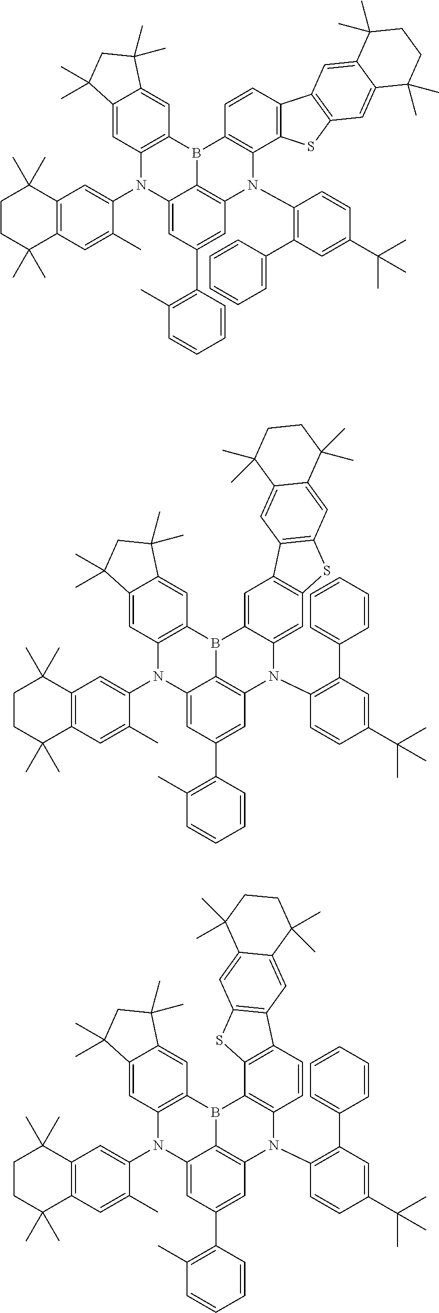 [SMILES: Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1ccccc1-c1cc2c3c(c1)N(c1ccc(C(C)(C)C)cc1-c1ccccc1)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C]

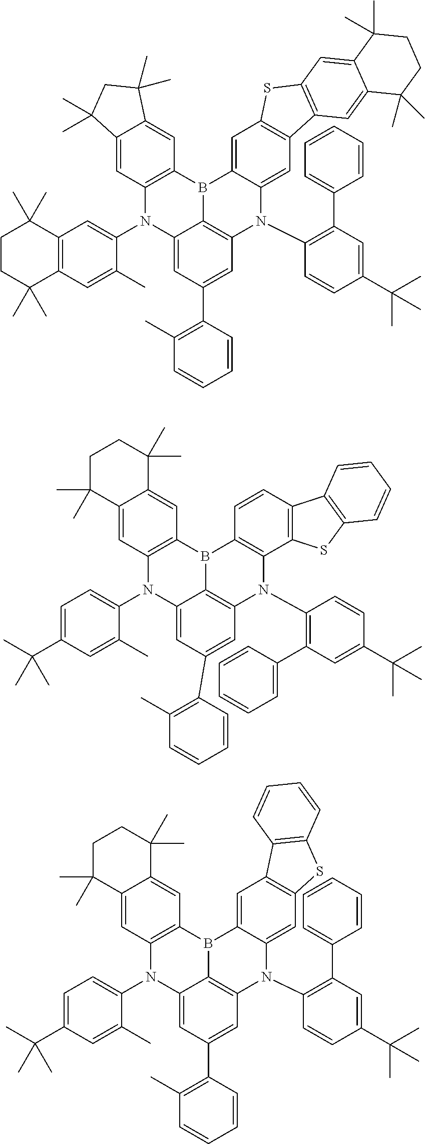

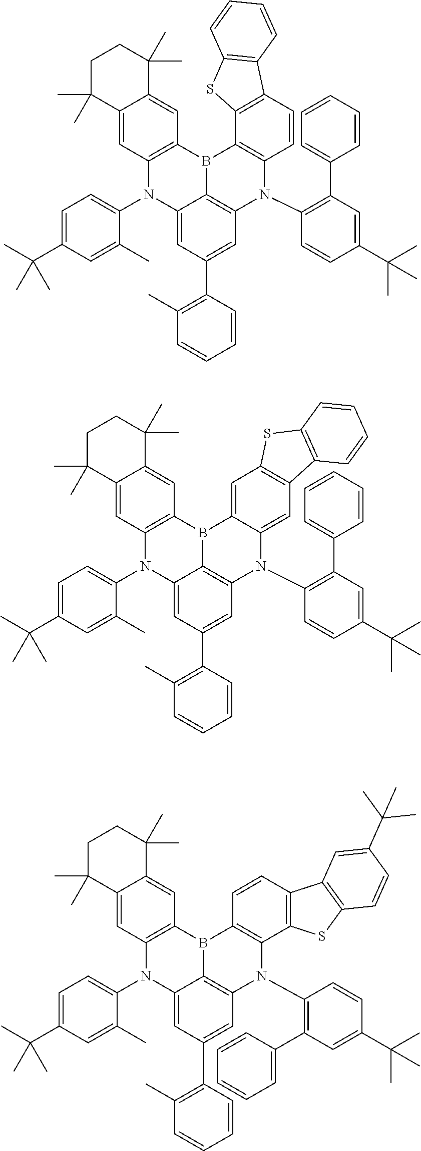

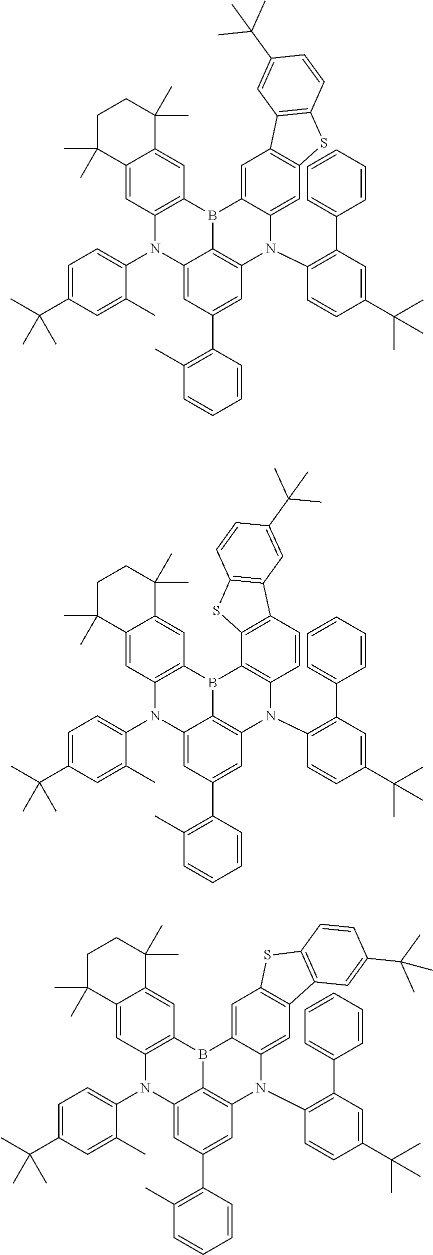

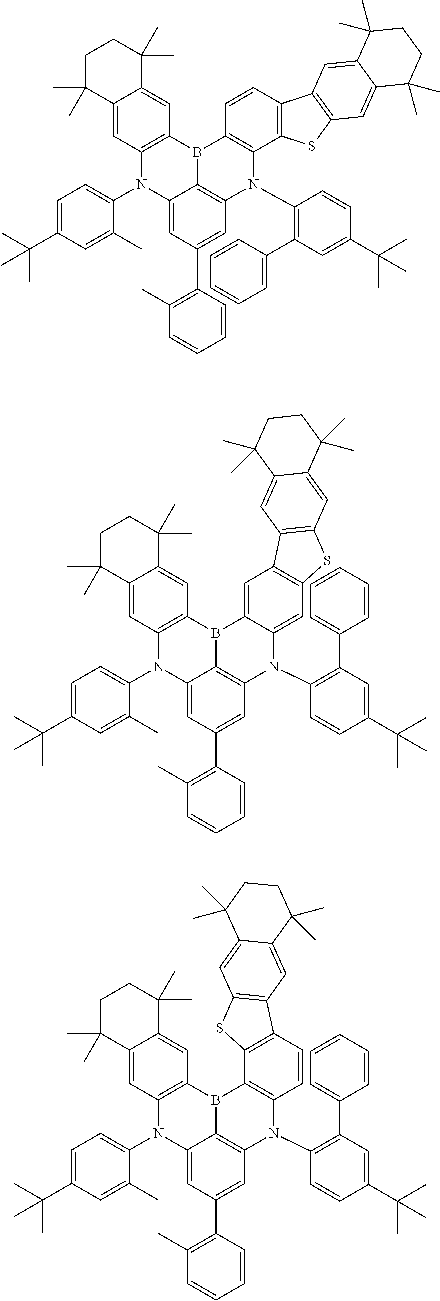

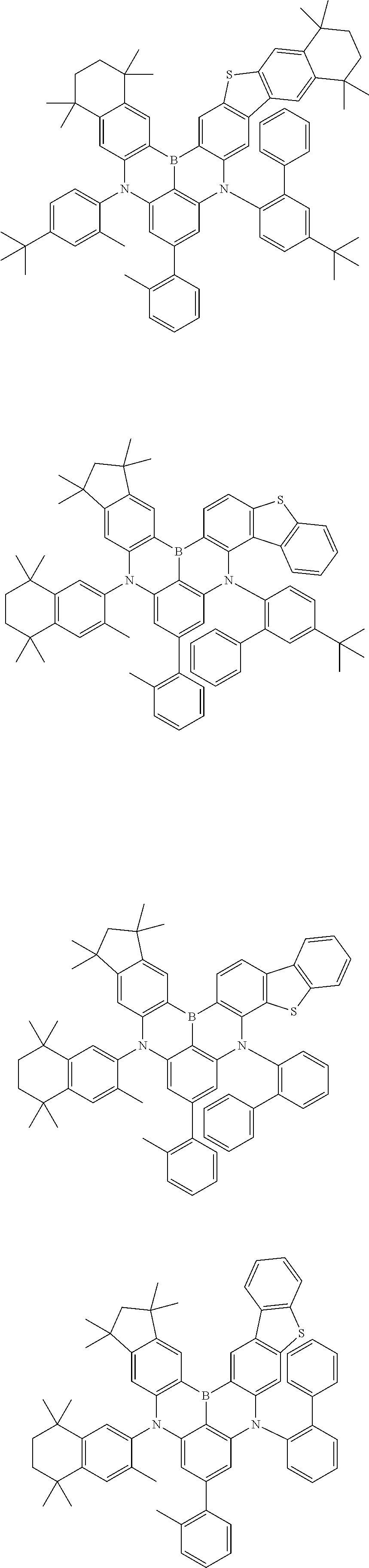

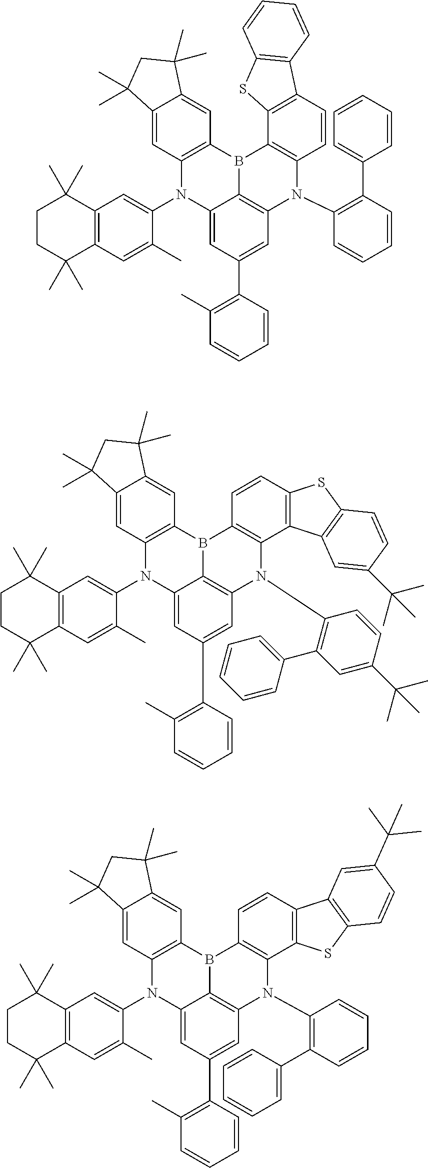 [SMILES: Cc1ccccc1-c1cc2c3c(c1)N(c1ccccc1-c1ccccc1)c1ccc4c(sc5ccccc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)CC3(C)C]

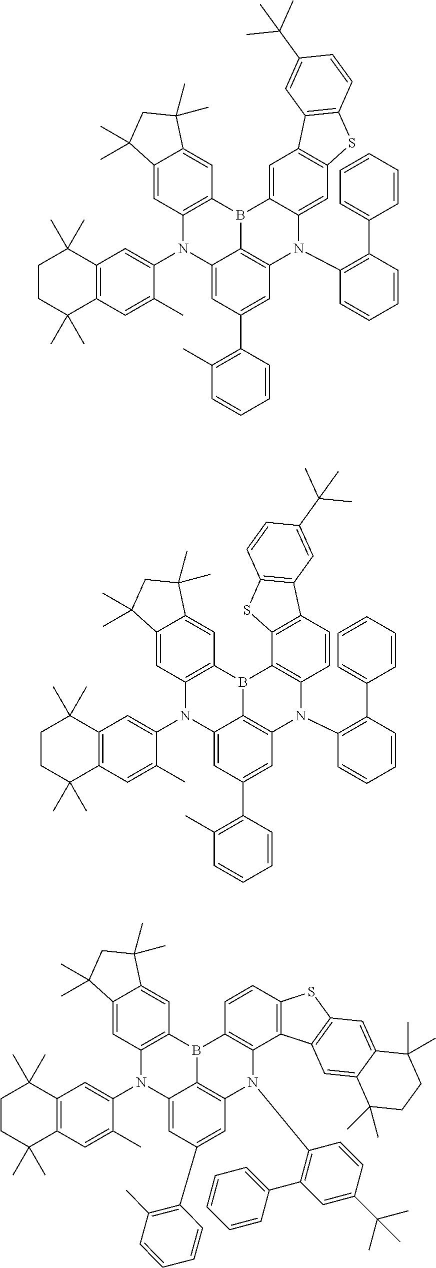 [SMILES: Cc1ccccc1-c1cc2c3c(c1)N(c1ccccc1-c1ccccc1)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C]

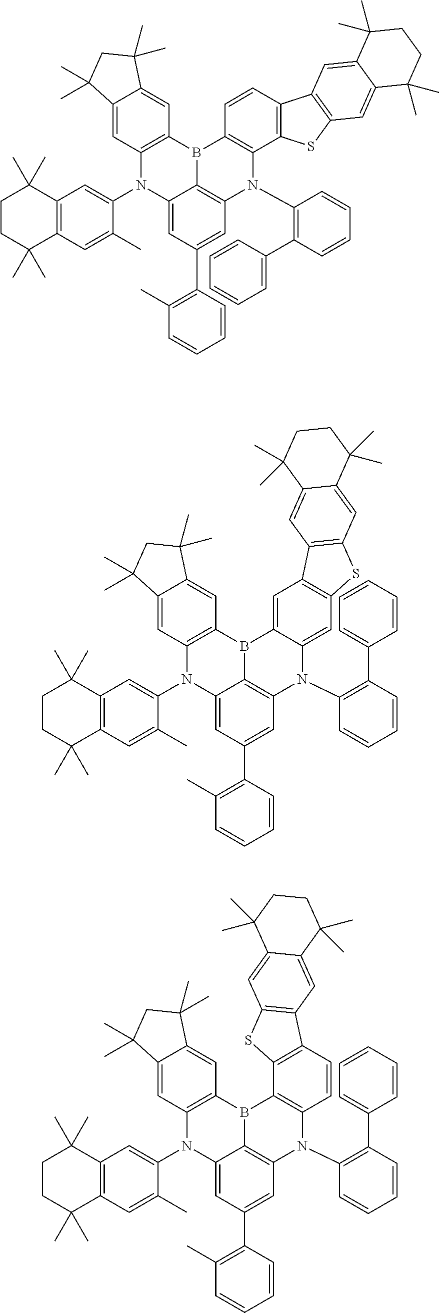 [SMILES: Cc1ccccc1-c1cc2c3c(c1)N(c1ccccc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C ; Cc1ccccc1-c1cc2c3c(c1)N(c1ccccc1-c1ccccc1)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C]

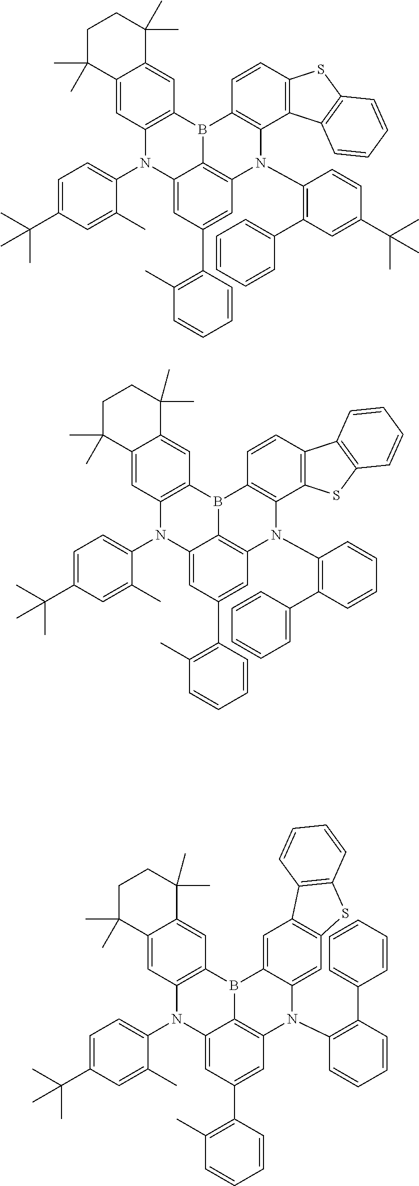

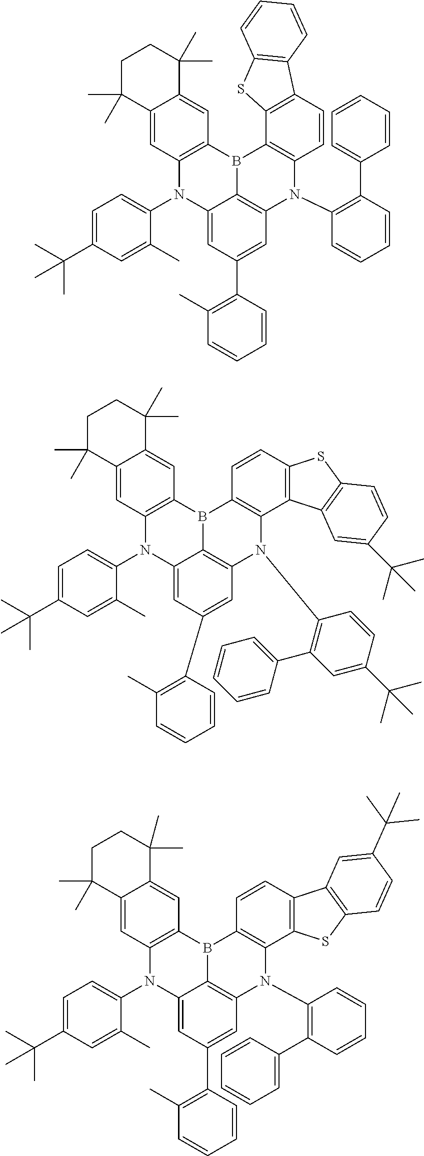

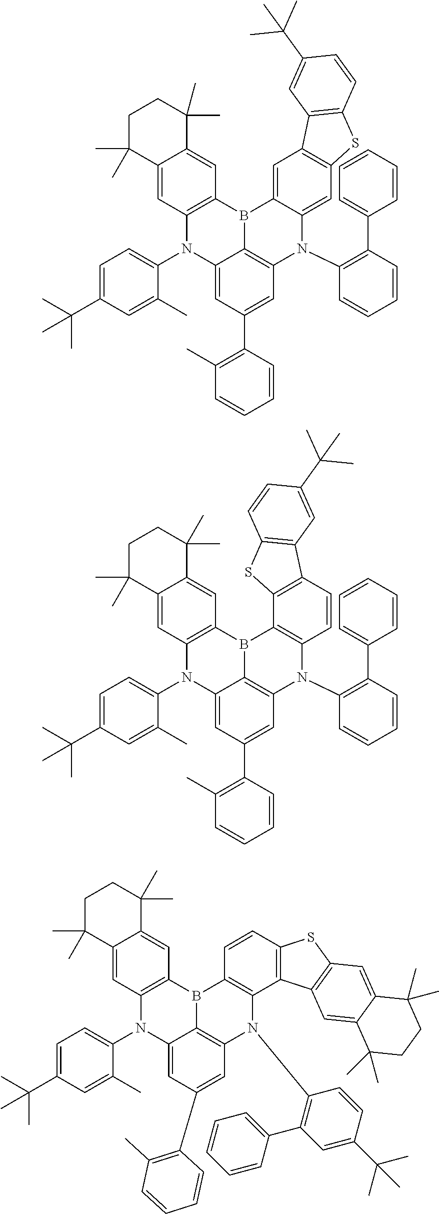

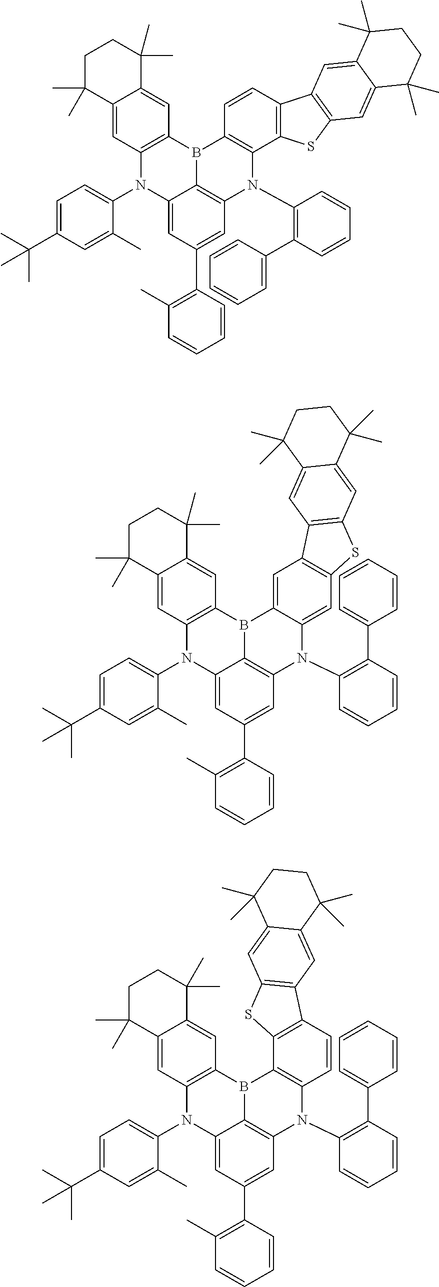

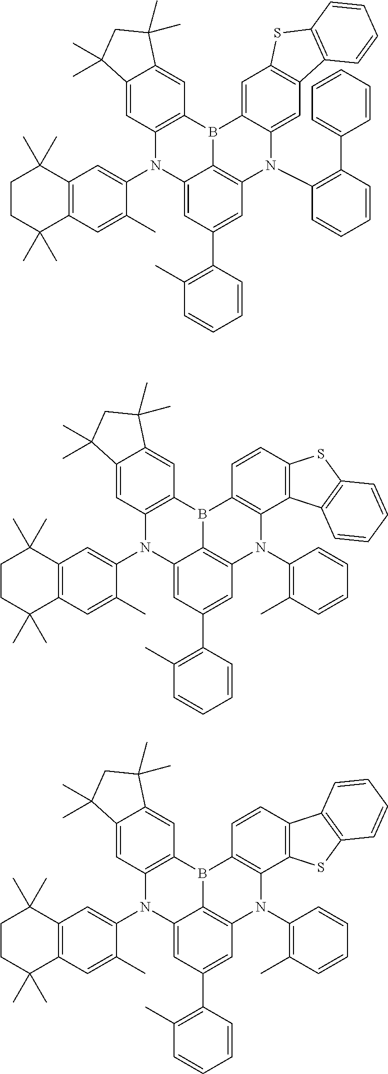 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1ccccc14 ; Cc1ccccc1-c1cc2c3c(c1)N(c1ccccc1C)c1c(ccc4sc5ccccc5c14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)CC3(C)C]

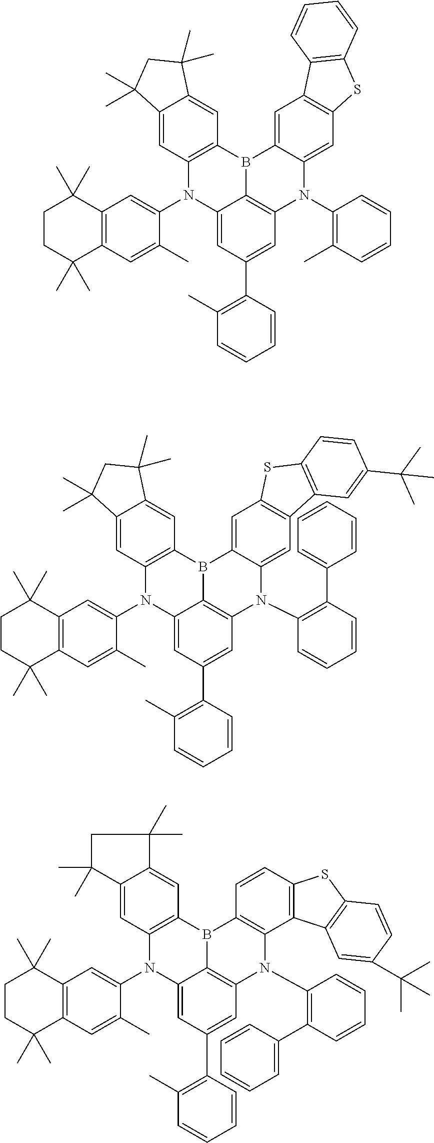 [SMILES: Cc1ccccc1-c1cc2c3c(c1)N(c1ccccc1C)c1cc4sc5ccccc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1ccc(C(C)(C)C)cc14 ; Cc1ccccc1-c1cc2c3c(c1)N(c1ccccc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)CC3(C)C]

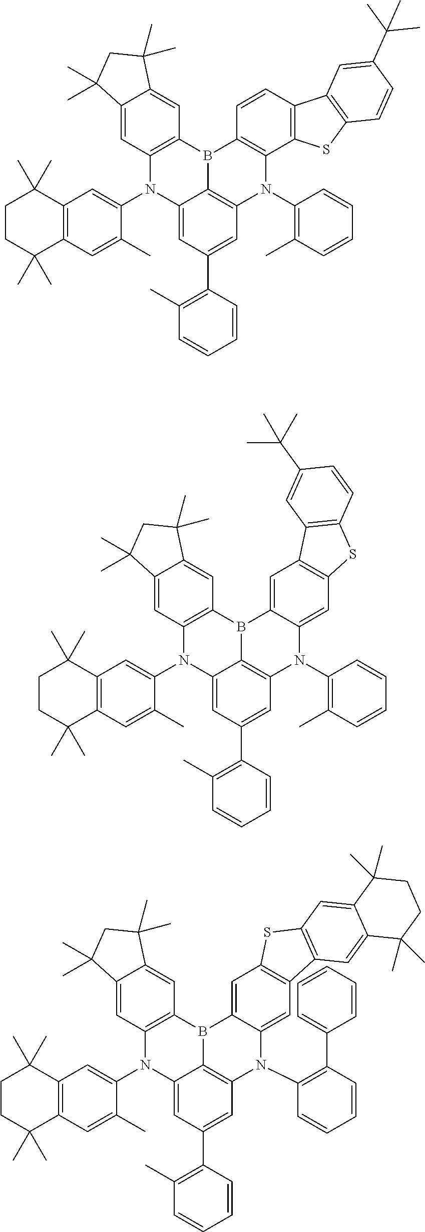 [SMILES: Cc1ccccc1-c1cc2c3c(c1)N(c1ccccc1C)c1c(ccc4c1sc1ccc(C(C)(C)C)cc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C]

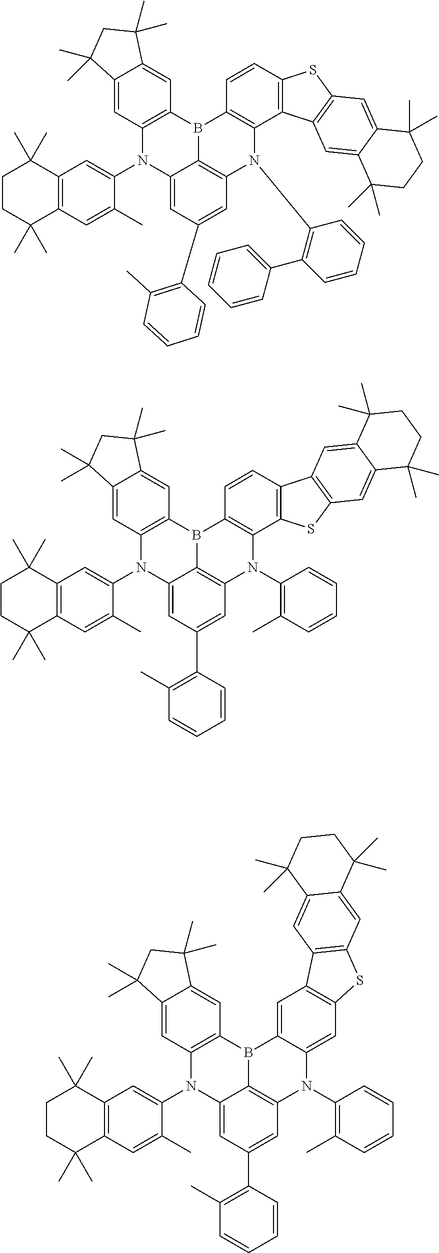 [SMILES: Cc1ccccc1-c1cc2c3c(c1)N(c1ccccc1-c1ccccc1)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C]

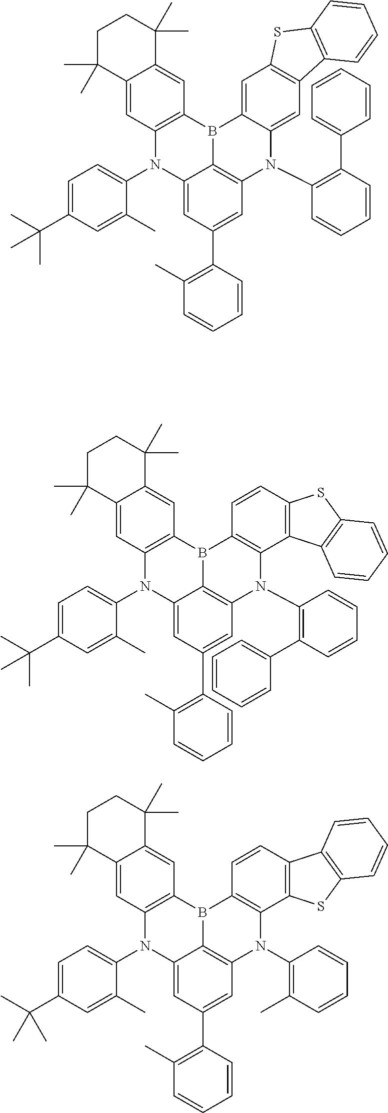

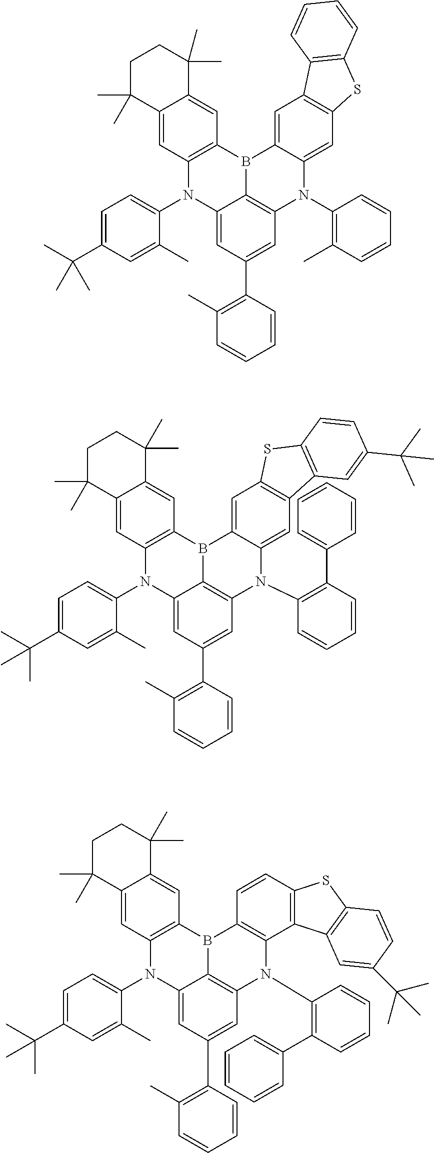

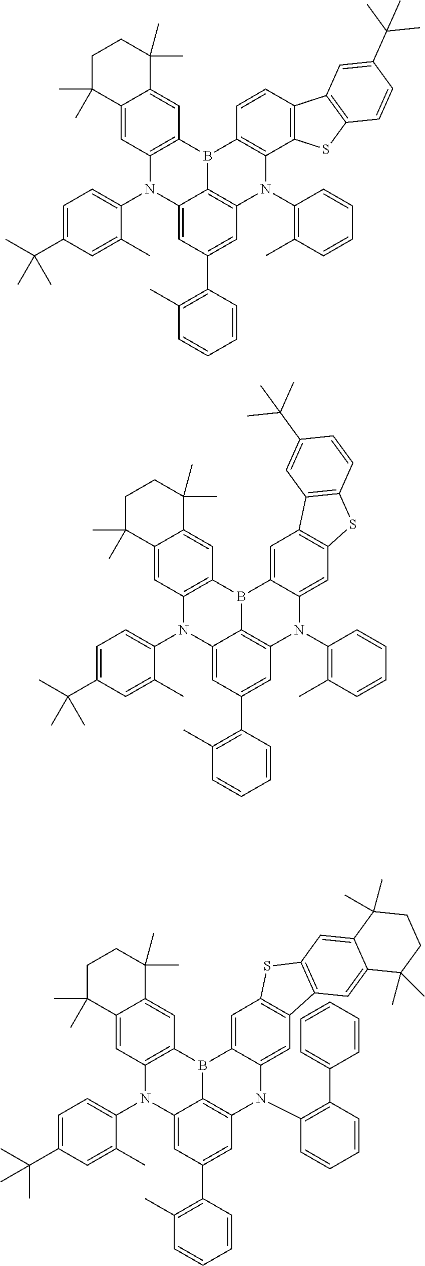

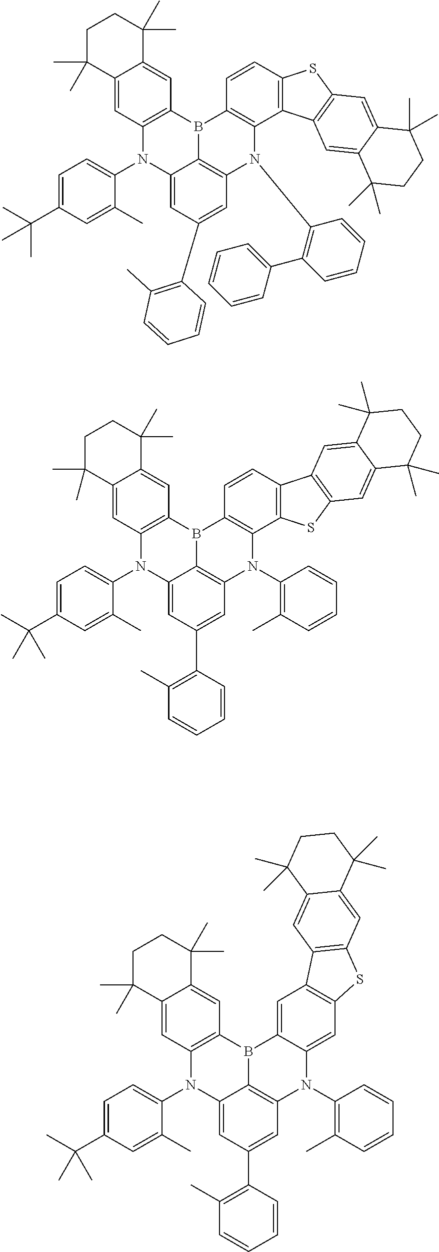

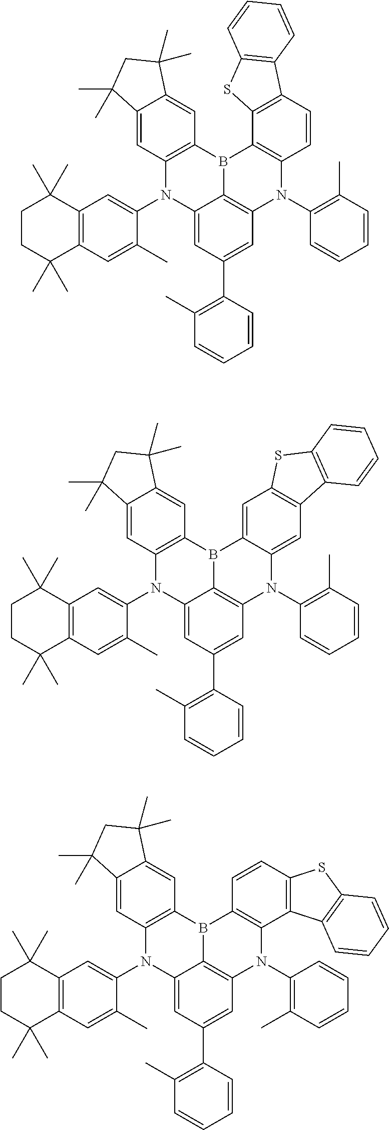 [SMILES: Cc1ccccc1-c1cc2c3c(c1)N(c1ccccc1C)c1ccc4c(sc5ccccc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1ccccc14 ; Cc1ccccc1-c1cc2c3c(c1)N(c1ccccc1C)c1c(ccc4sc5ccccc5c14)B3c1cc3c(cc1N2c1cc2c(cc1C)C(C)(C)CCC2(C)C)C(C)(C)CC3(C)C]

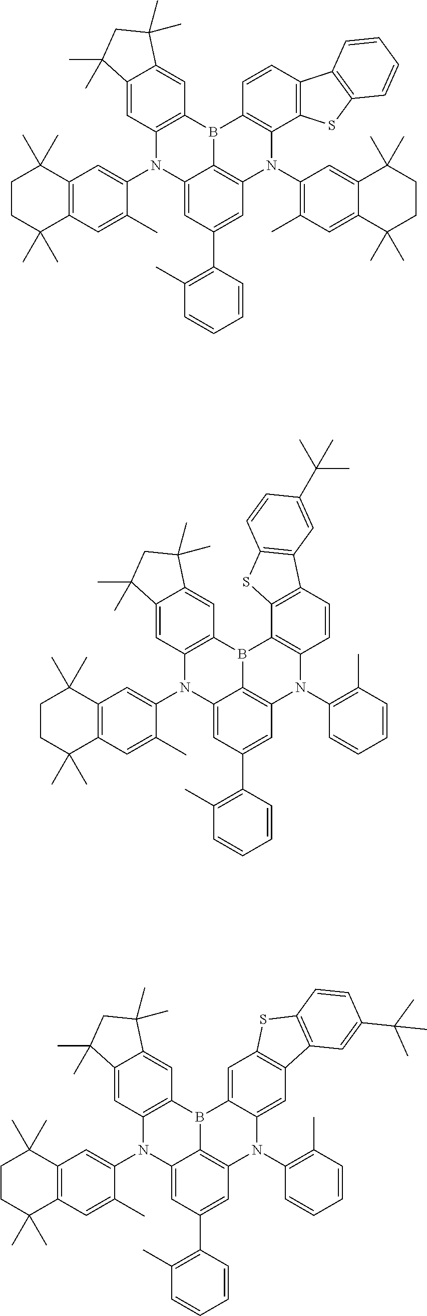 [SMILES: Cc1ccccc1-c1cc2c3c(c1)N(c1cc4c(cc1C)C(C)(C)CCC4(C)C)c1c(ccc4c1sc1ccccc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1ccc4c(sc5ccc(C(C)(C)C)cc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1ccc(C(C)(C)C)cc14]

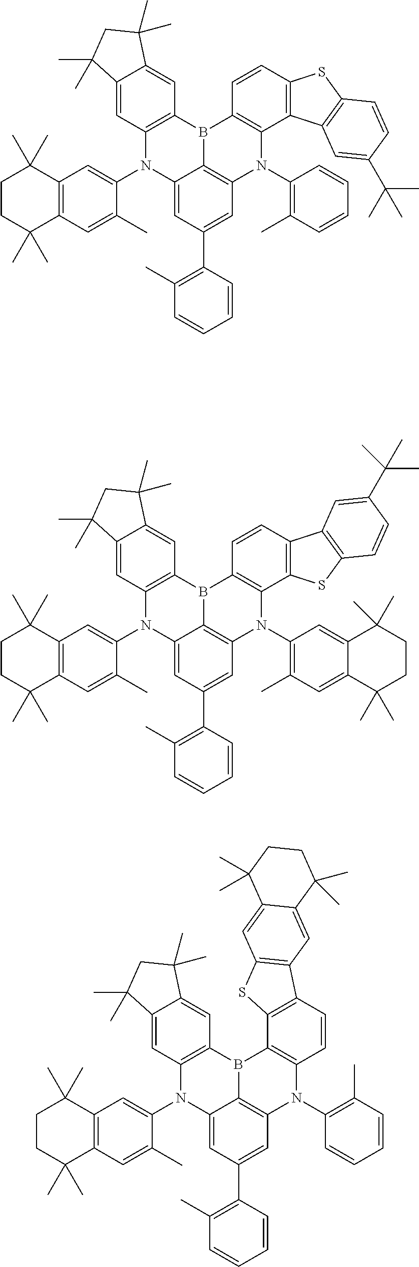 [SMILES: Cc1ccccc1-c1cc2c3c(c1)N(c1ccccc1C)c1c(ccc4sc5ccc(C(C)(C)C)cc5c14)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1c(ccc4c1sc1ccc(C(C)(C)C)cc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C]

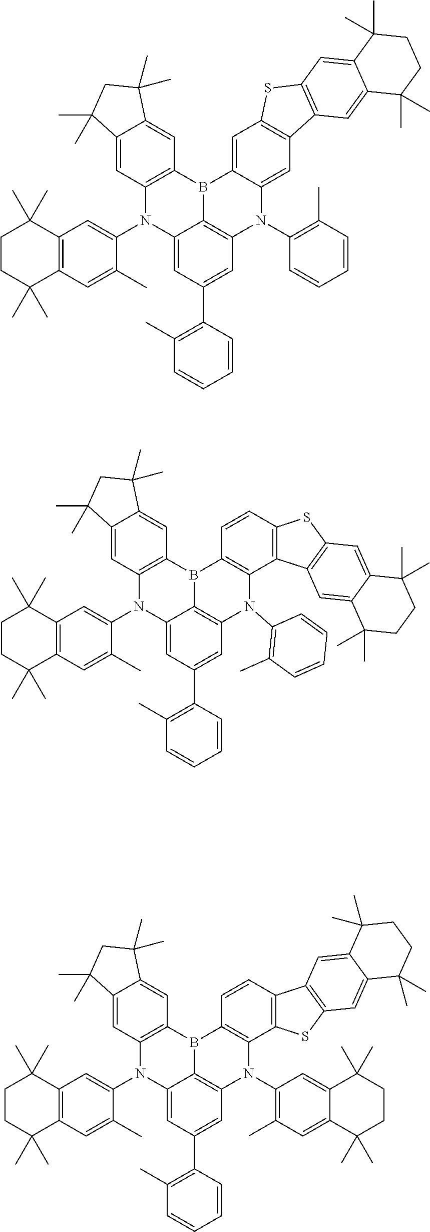 [SMILES: Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C ; Cc1ccccc1-c1cc2c3c(c1)N(c1ccccc1C)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C]

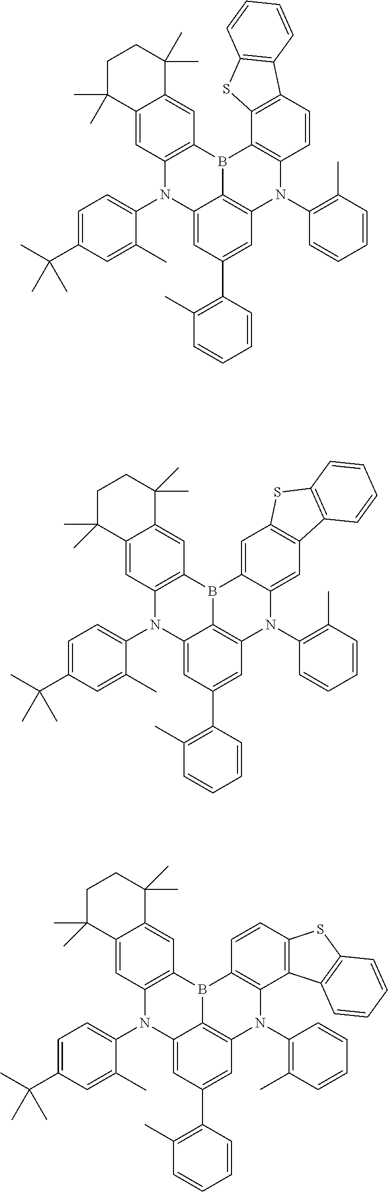 [SMILES: Cc1ccccc1-c1cc2c3c(c1)N(c1ccccc1C)c1ccc4c(sc5ccccc54)c1B3c1cc3c(cc1N2c1ccc(C(C)(C)C)cc1C)C(C)(C)CCC3(C)C ; Cc1ccccc1-c1cc2c3c(c1)N(c1ccccc1C)c1cc4c(cc1B3c1cc3c(cc1N2c1ccc(C(C)(C)C)cc1C)C(C)(C)CCC3(C)C)sc1ccccc14 ; Cc1ccccc1-c1cc2c3c(c1)N(c1ccccc1C)c1c(ccc4sc5ccccc5c14)B3c1cc3c(cc1N2c1ccc(C(C)(C)C)cc1C)C(C)(C)CCC3(C)C]

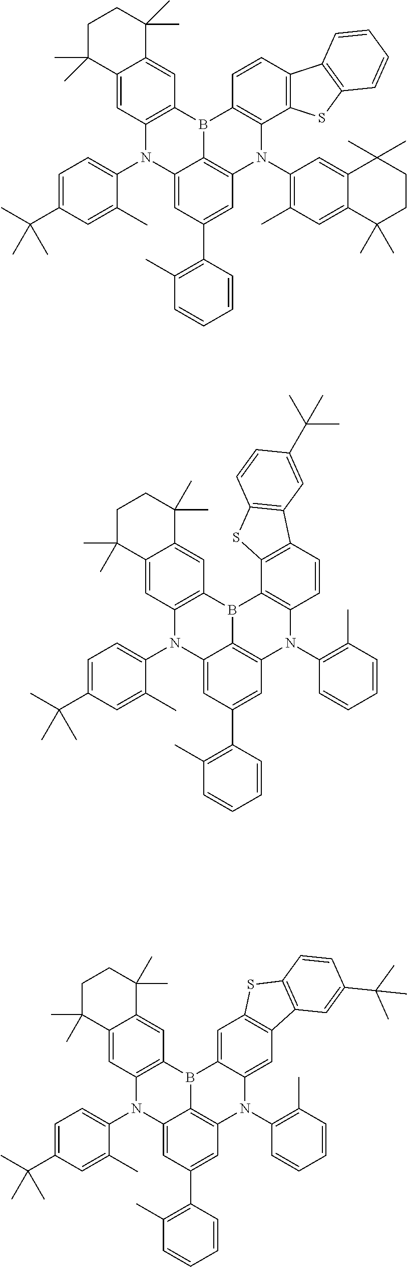

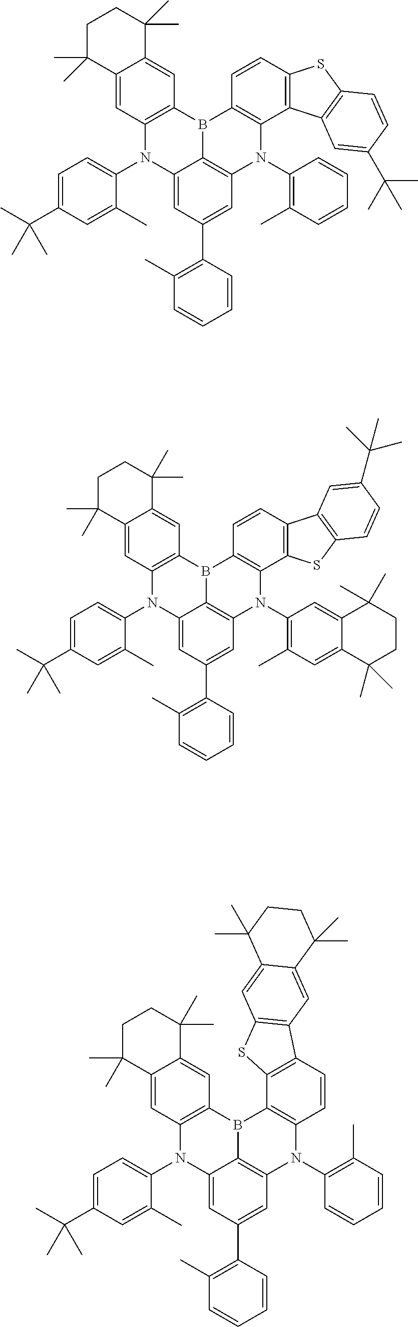

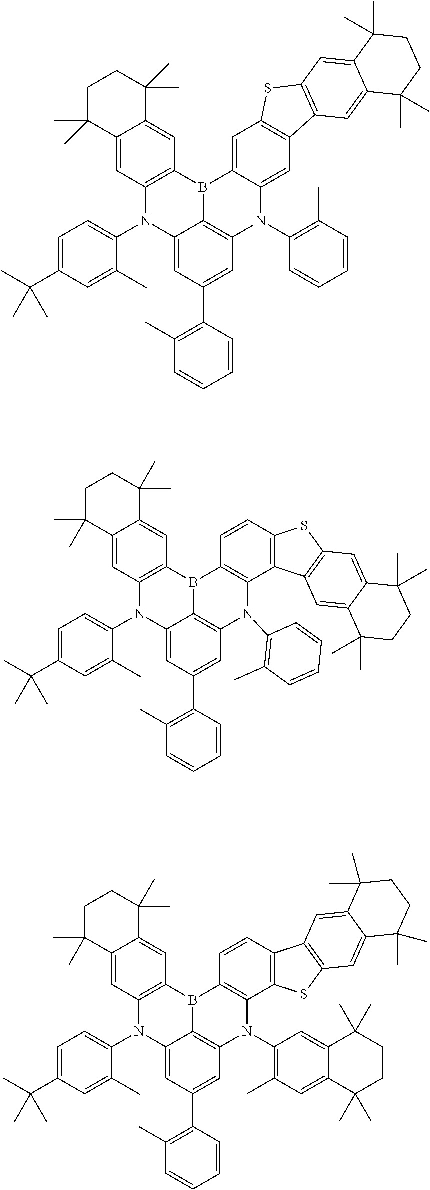

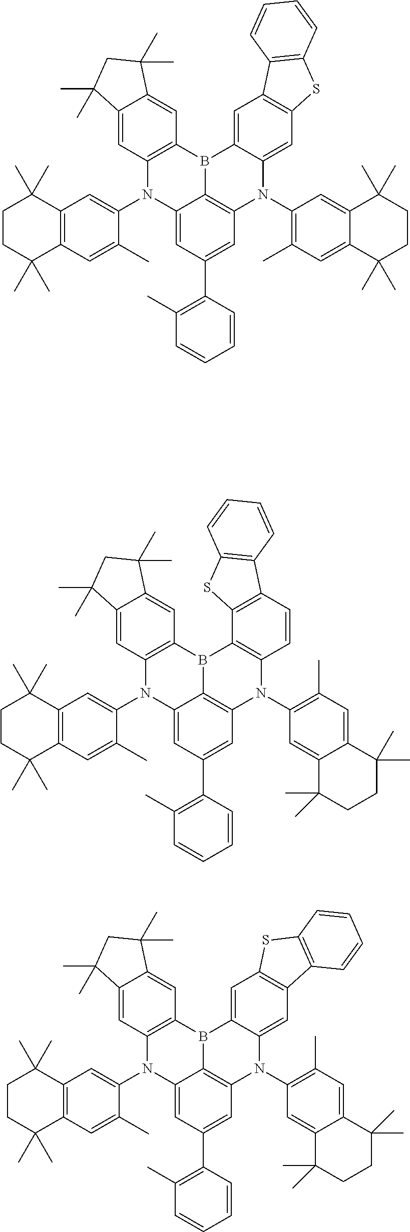 [SMILES: Cc1ccccc1-c1cc2c3c(c1)N(c1cc4c(cc1C)C(C)(C)CCC4(C)C)c1cc4sc5ccccc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1ccc4c(sc5ccccc54)c1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)sc1ccccc14]

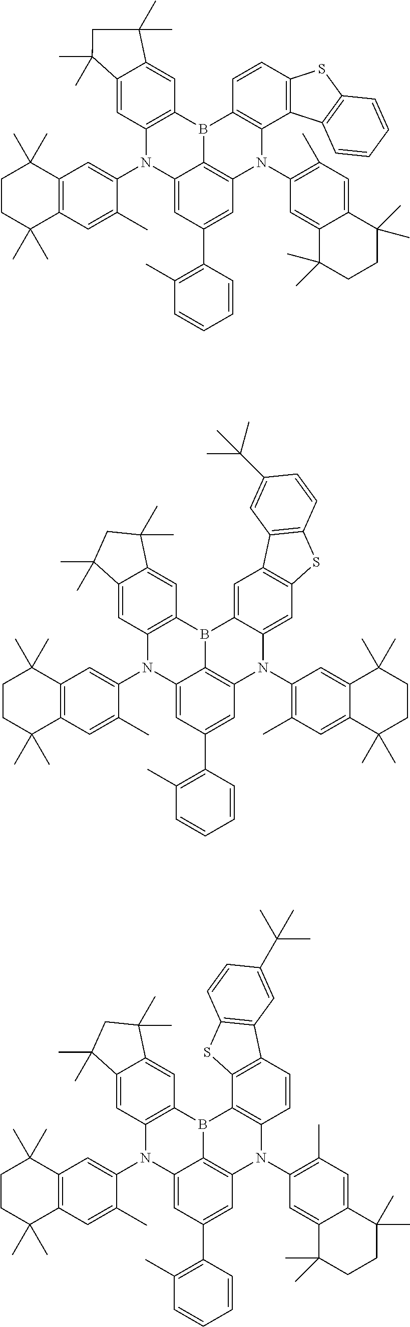 [SMILES: Cc1ccccc1-c1cc2c3c(c1)N(c1cc4c(cc1C)C(C)(C)CCC4(C)C)c1c(ccc4sc5ccccc5c14)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1ccc4c(sc5ccc(C(C)(C)C)cc54)c1B3c1cc3c(cc1N2c1cc2c(cc1C)C(C)(C)CCC2(C)C)C(C)(C)CC3(C)C]

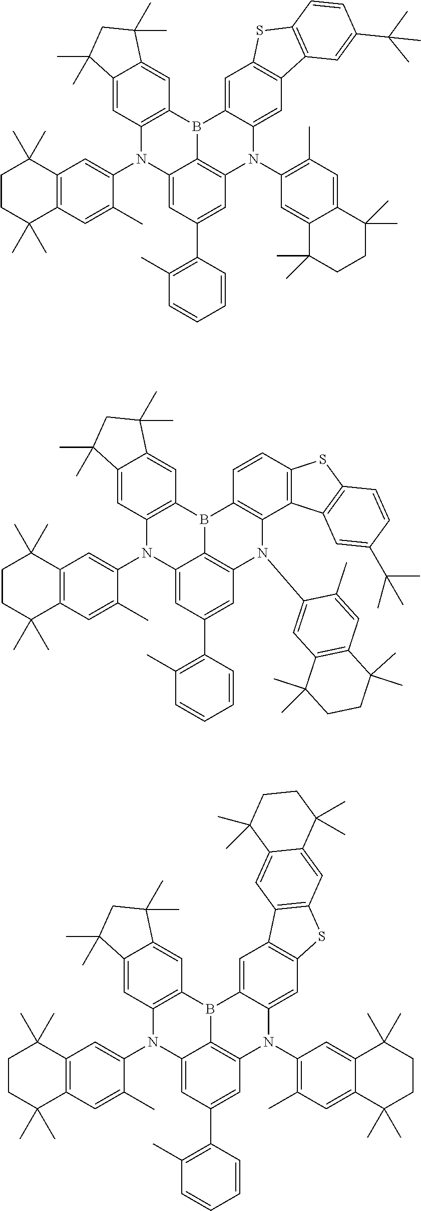 [SMILES: Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)sc1ccc(C(C)(C)C)cc14 ; Cc1ccccc1-c1cc2c3c(c1)N(c1cc4c(cc1C)C(C)(C)CCC4(C)C)c1c(ccc4sc5ccc(C(C)(C)C)cc5c14)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C]

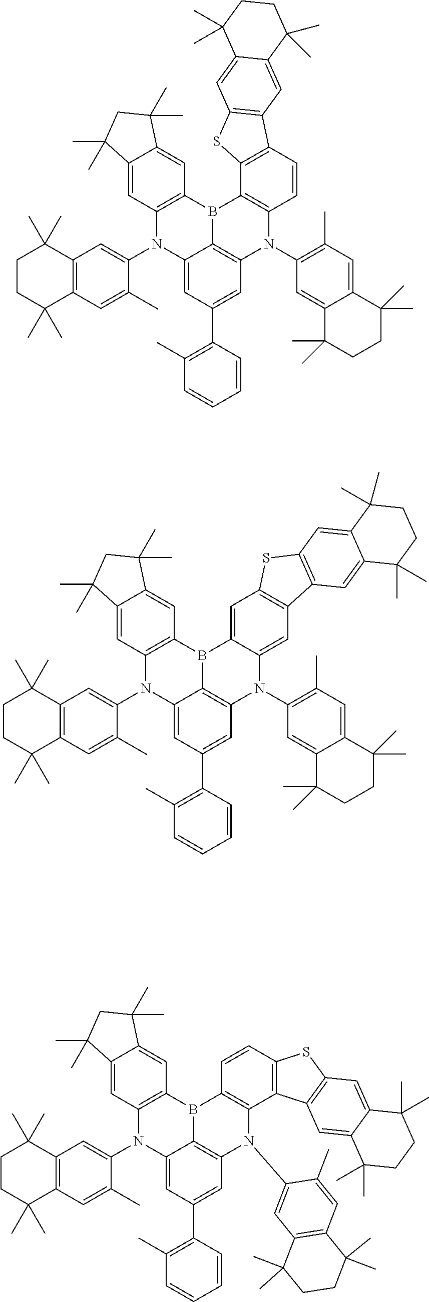 [SMILES: Cc1ccccc1-c1cc2c3c(c1)N(c1cc4c(cc1C)C(C)(C)CCC4(C)C)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C ; Cc1ccccc1-c1cc2c3c(c1)N(c1cc4c(cc1C)C(C)(C)CCC4(C)C)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C]

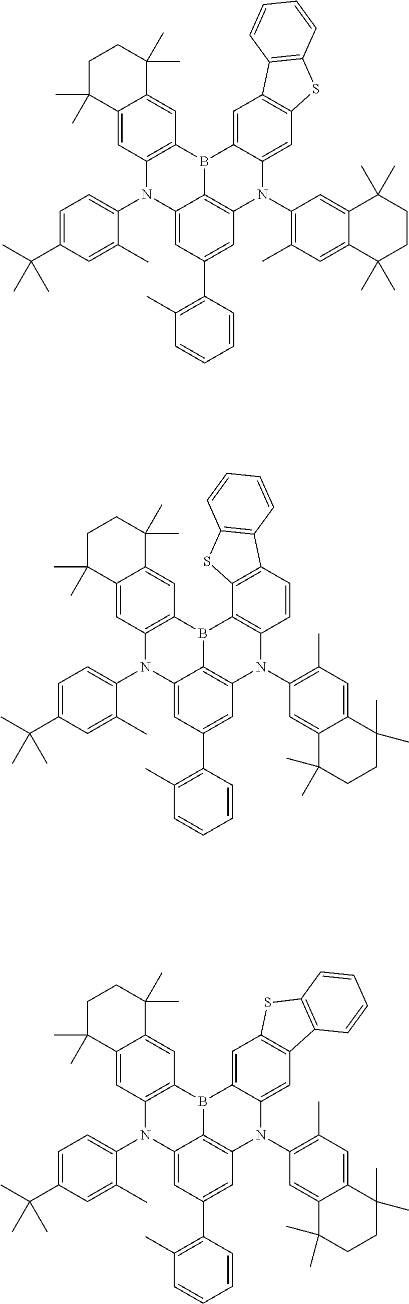

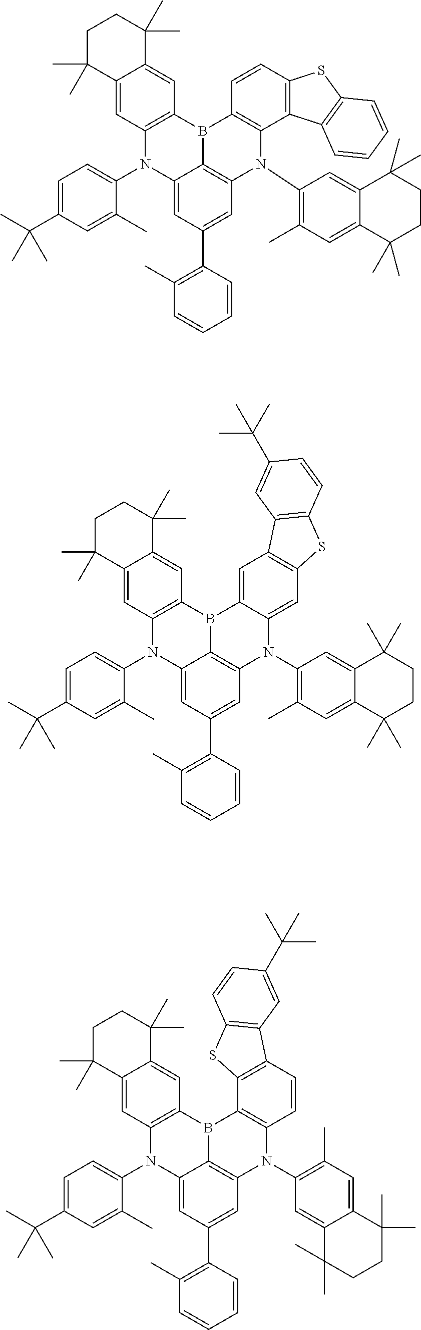

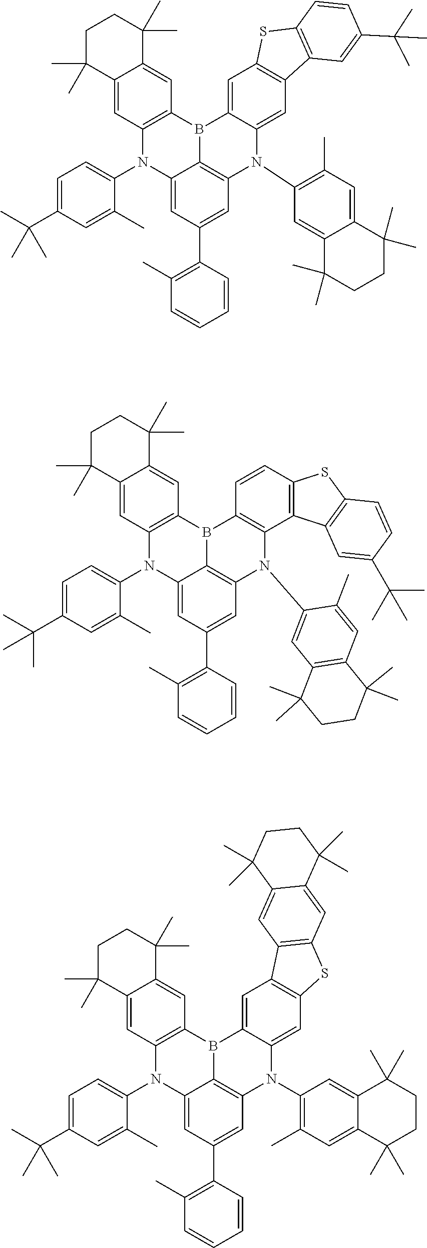

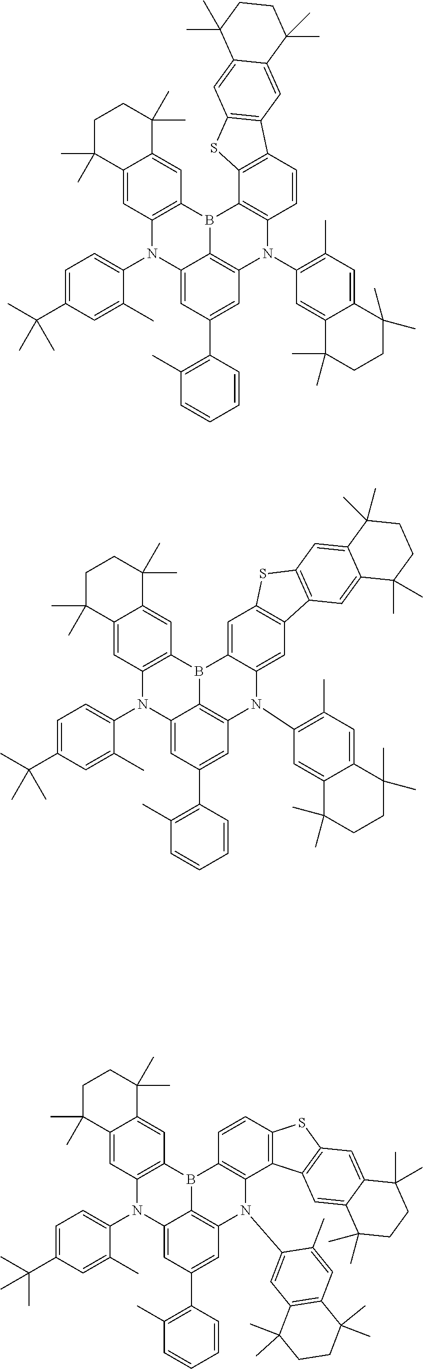

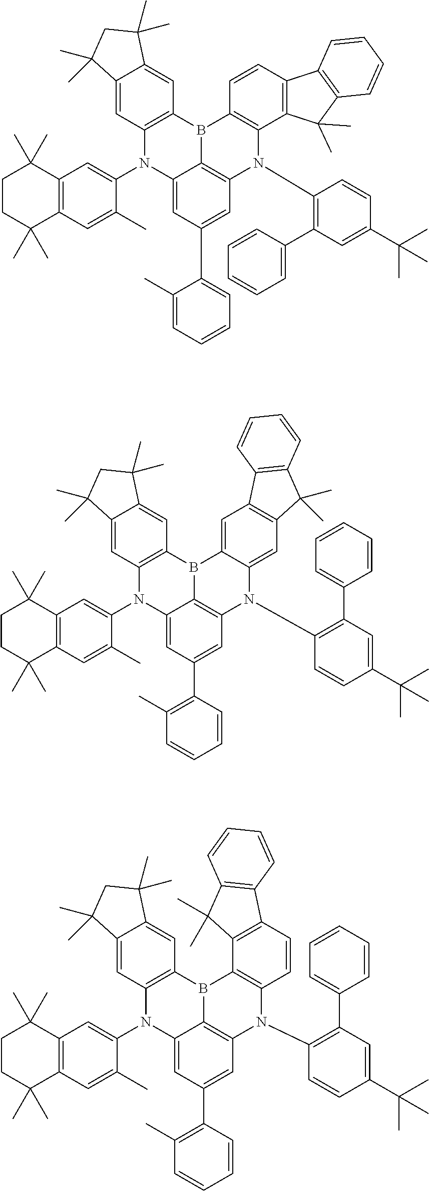 [SMILES: Cc1ccccc1-c1cc2c3c(c1)N(c1ccc(C(C)(C)C)cc1-c1ccccc1)c1c(ccc4c1C(C)(C)c1ccccc1-4)B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1ccccc1C4(C)C ; Cc1ccccc1-c1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1ccccc1-4]

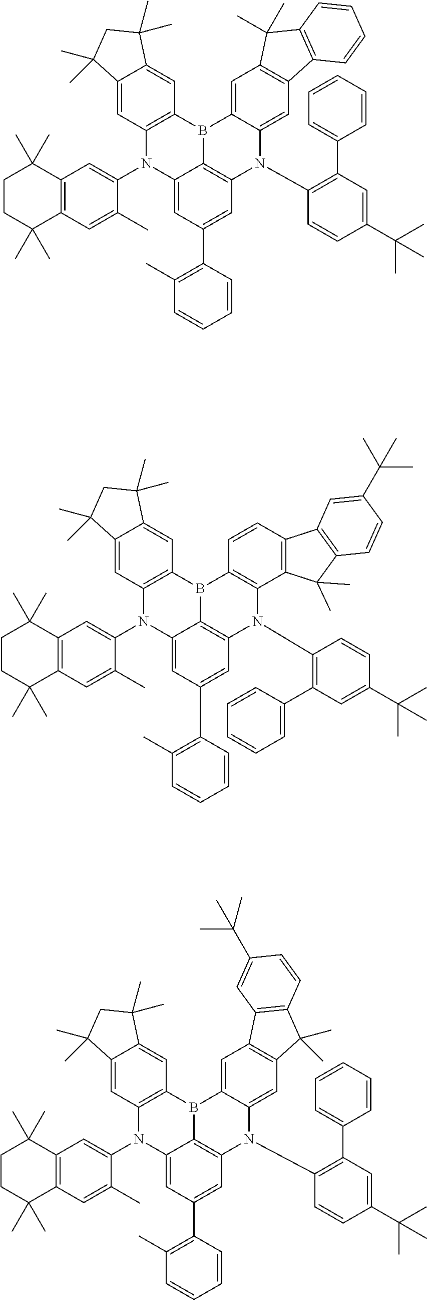 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1ccccc1-4 ; Cc1ccccc1-c1cc2c3c(c1)N(c1ccc(C(C)(C)C)cc1-c1ccccc1)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C]

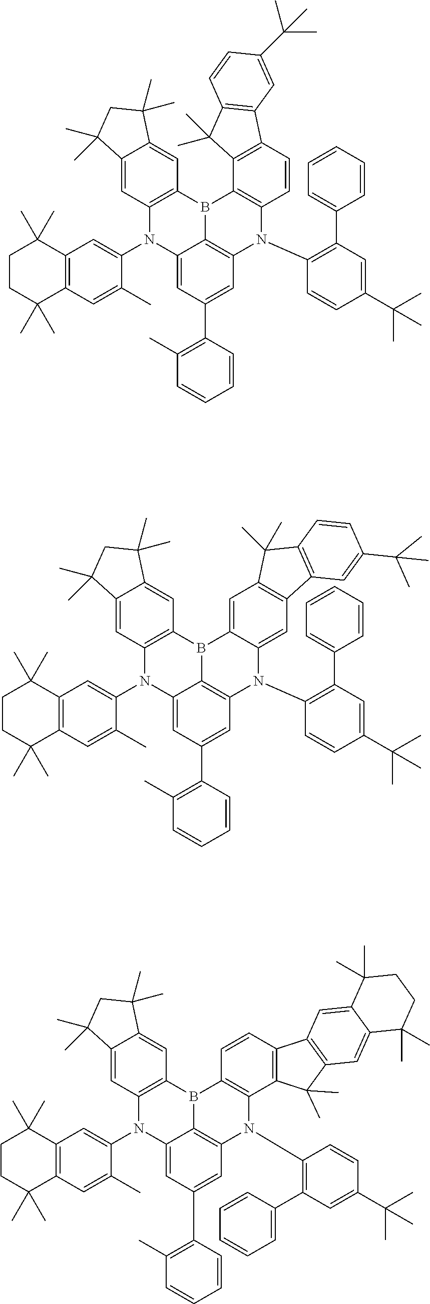 [SMILES: Cc1ccccc1-c1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C]

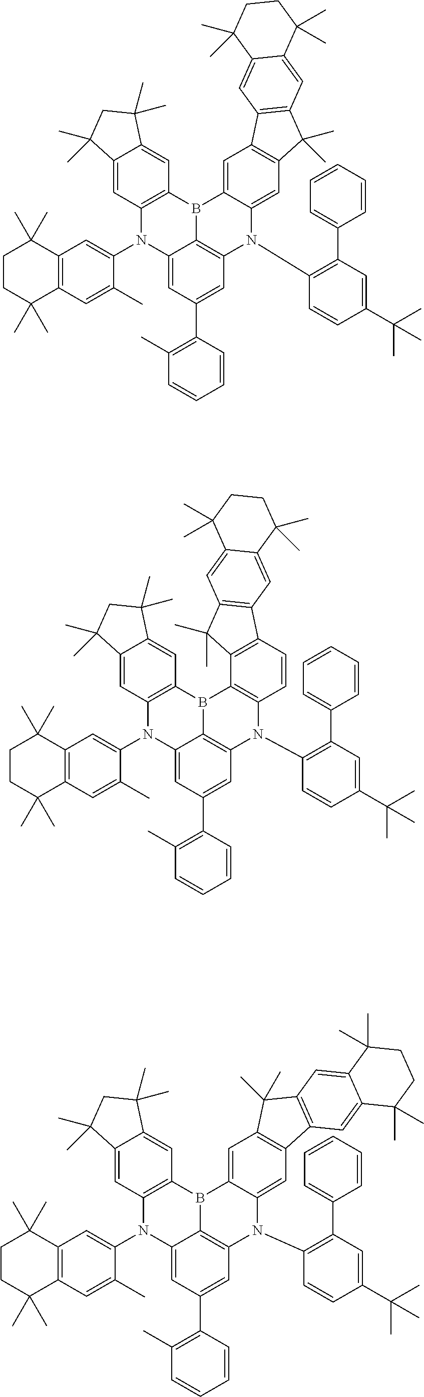 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1ccccc1-c1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

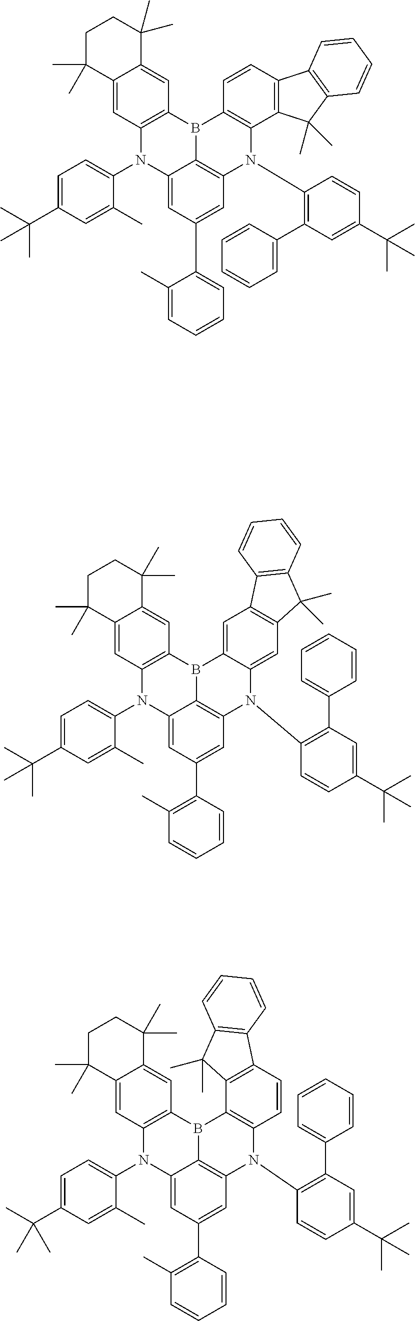

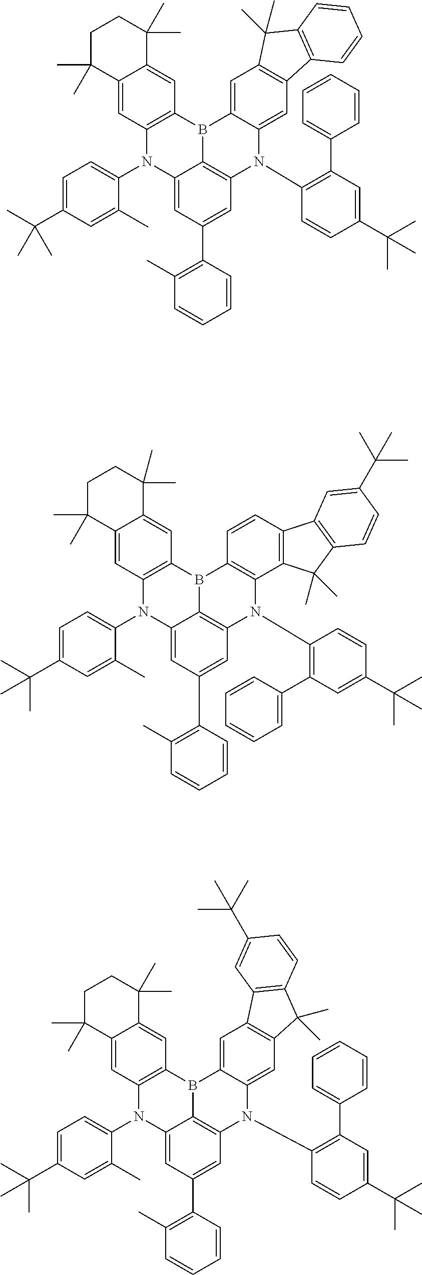

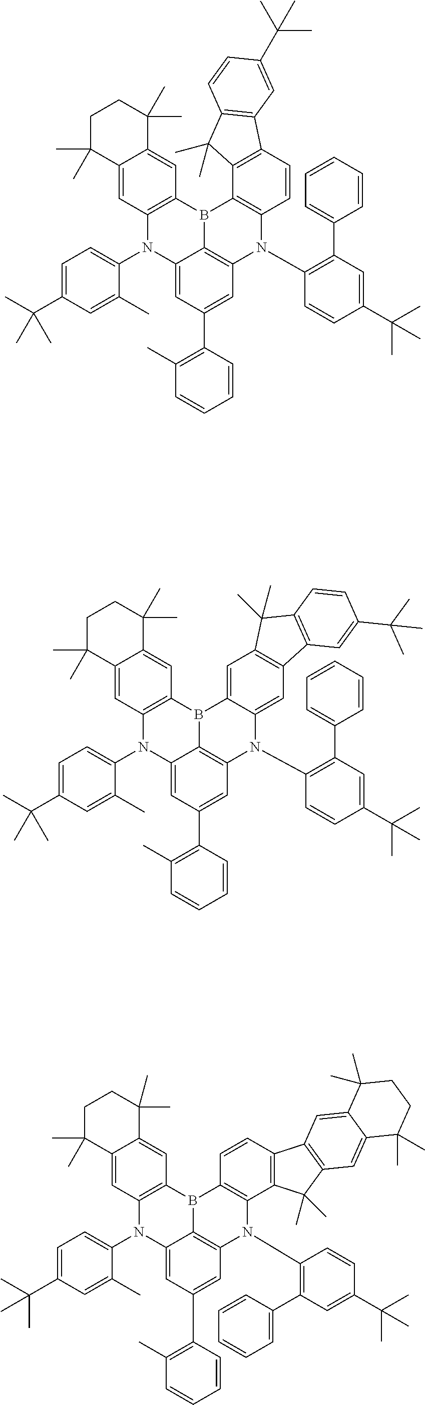

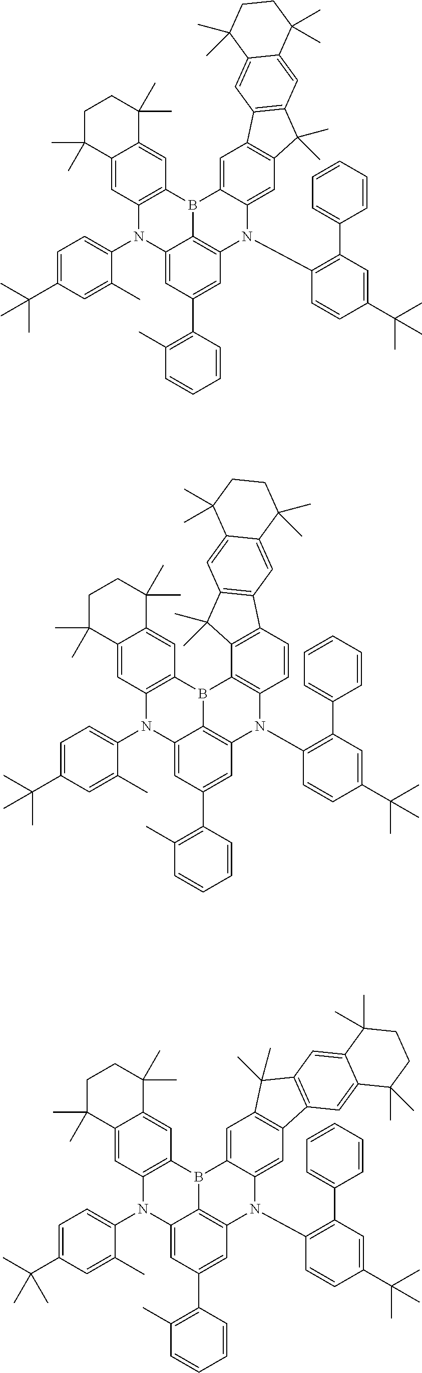

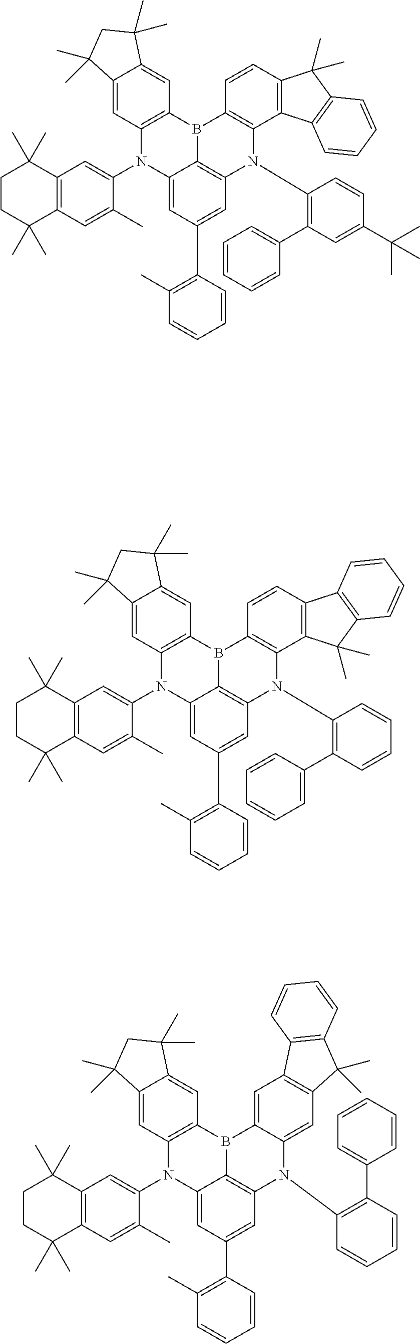 [SMILES: Cc1ccccc1-c1cc2c3c(c1)N(c1ccc(C(C)(C)C)cc1-c1ccccc1)c1c(ccc4c1-c1ccccc1C4(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1c(ccc4c1C(C)(C)c1ccccc1-4)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)-c1ccccc1C4(C)C]

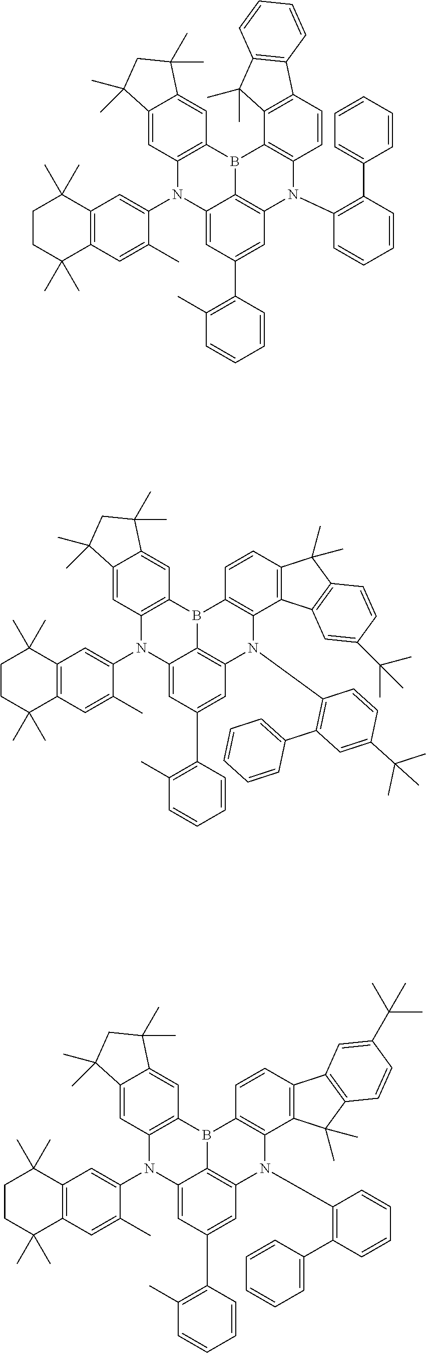 [SMILES: Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1ccccc1-4 ; Cc1ccccc1-c1cc2c3c(c1)N(c1ccc(C(C)(C)C)cc1-c1ccccc1)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C]

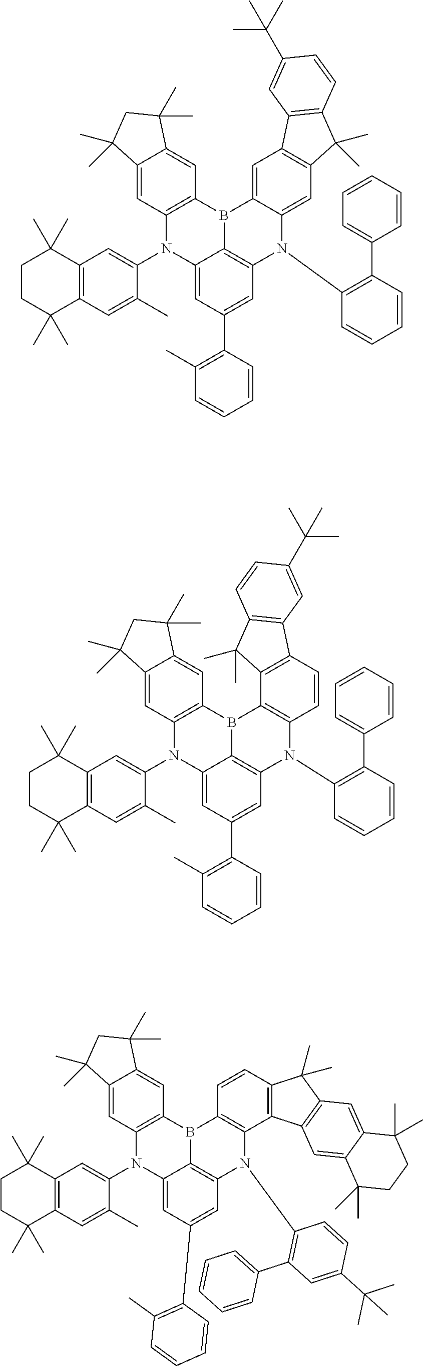 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C ; Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C]

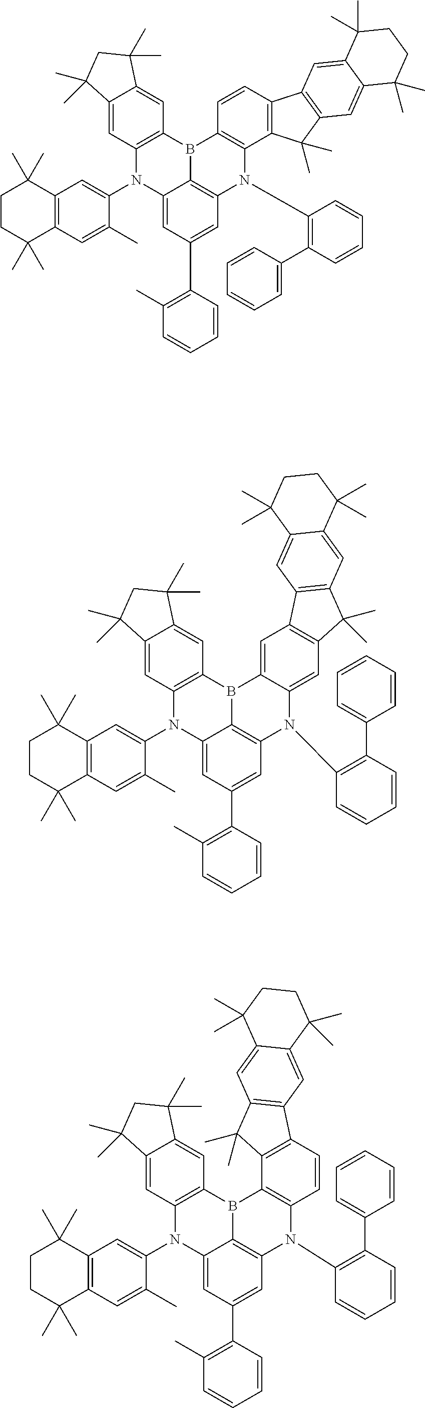 [SMILES: Cc1ccccc1-c1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

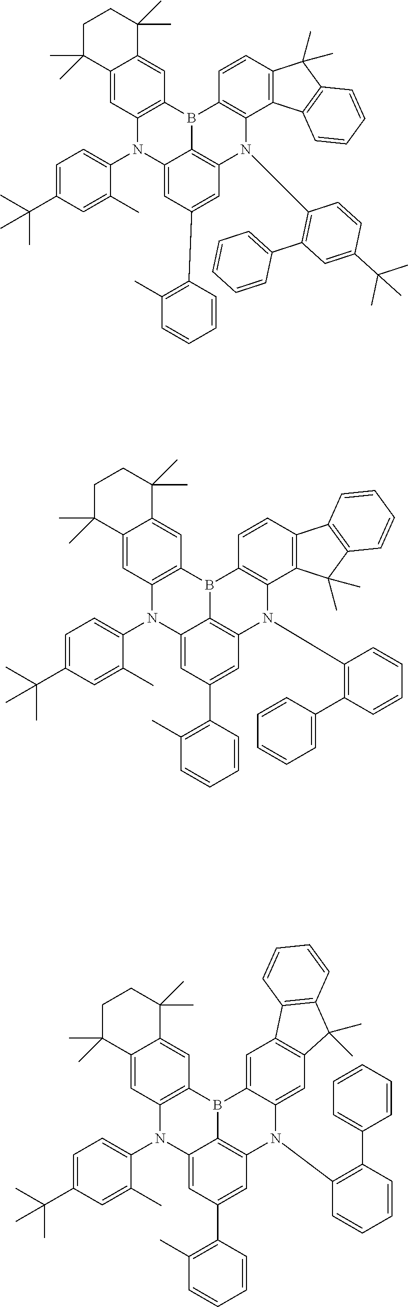

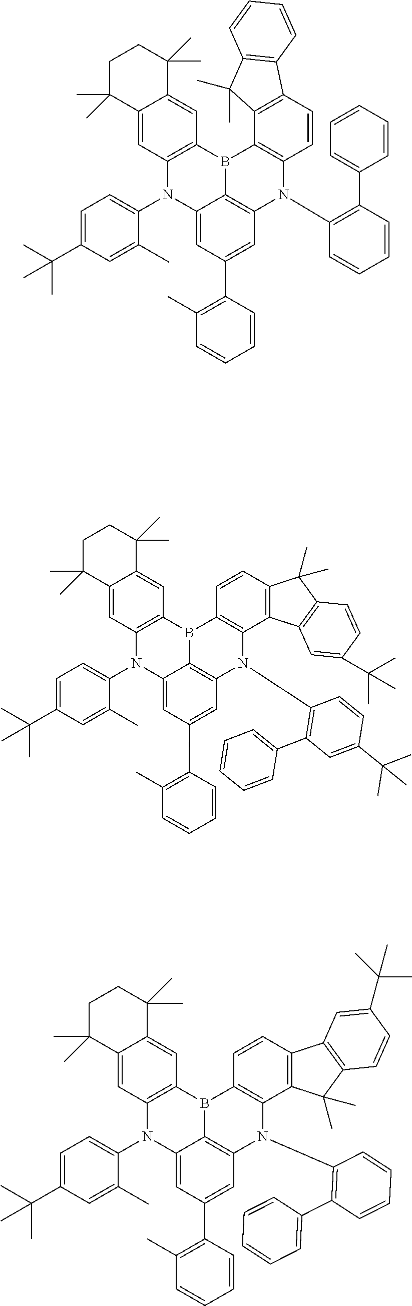

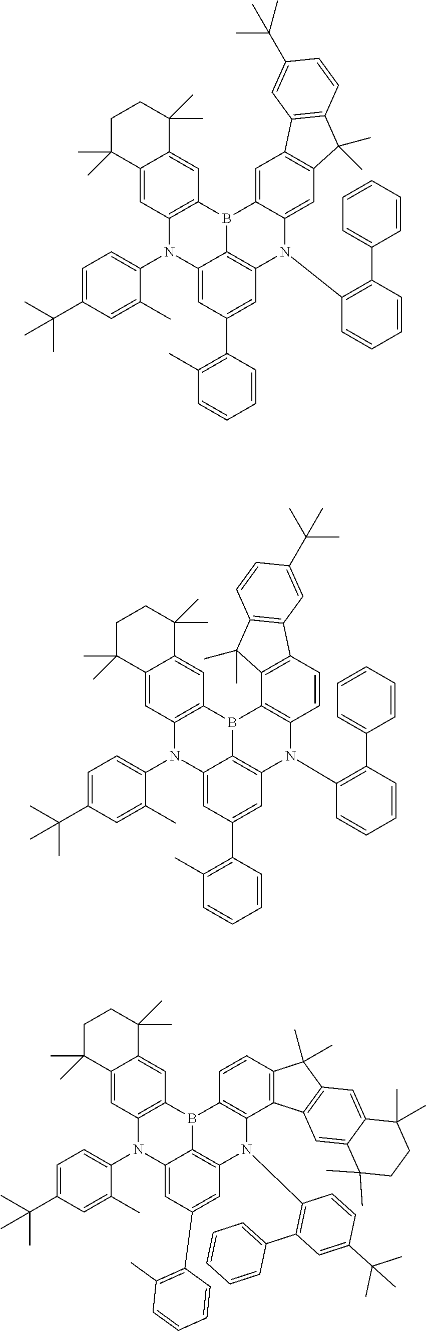 [SMILES: Cc1ccccc1-c1cc2c3c(c1)N(c1ccccc1-c1ccccc1)c1cc4c(cc1B3c1cc3c(cc1N2c1ccc(C(C)(C)C)cc1C)C(C)(C)CCC3(C)C)-c1cc(C(C)(C)C)ccc1C4(C)C ; Cc1ccccc1-c1cc2c3c(c1)N(c1ccccc1-c1ccccc1)c1ccc4c(c1B3c1cc3c(cc1N2c1ccc(C(C)(C)C)cc1C)C(C)(C)CCC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1ccc(C(C)(C)C)cc1C)C(C)(C)CCC3(C)C]

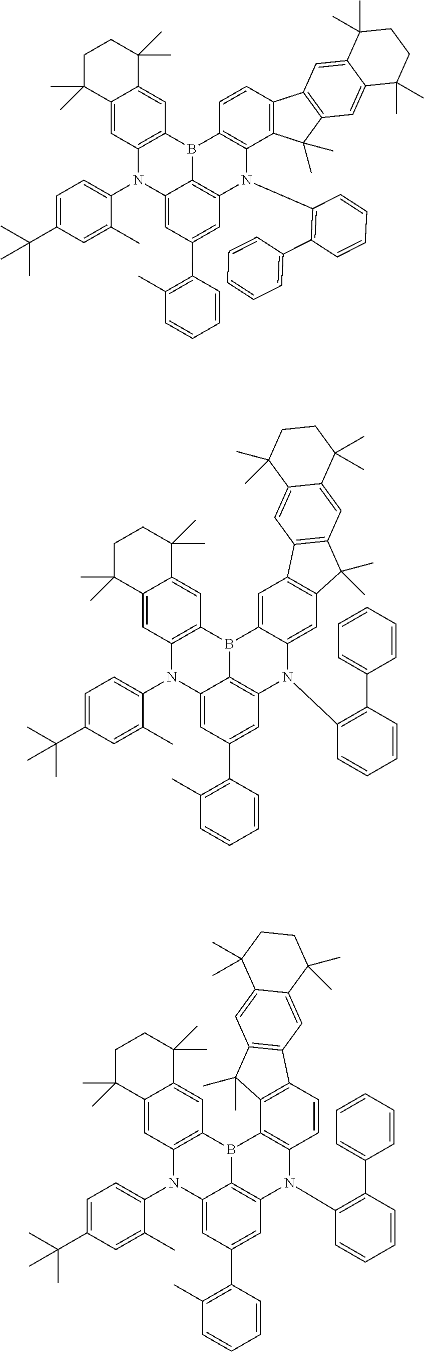

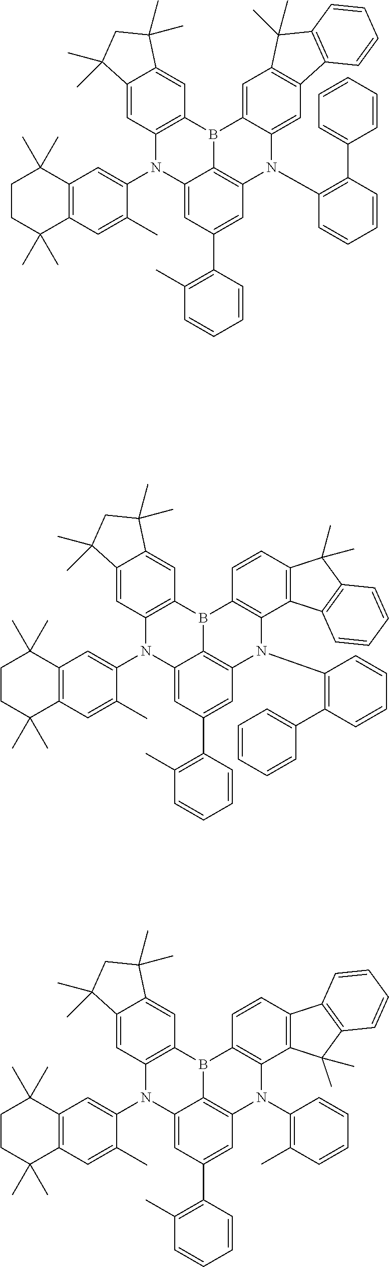 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)C(C)(C)c1ccccc1-4 ; Cc1ccccc1-c1cc2c3c(c1)N(c1ccccc1-c1ccccc1)c1c(ccc4c1-c1ccccc1C4(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1c(ccc4c1C(C)(C)c1ccccc1-4)B3c1cc3c(cc1N2c1cc2c(cc1C)C(C)(C)CCC2(C)C)C(C)(C)CC3(C)C]

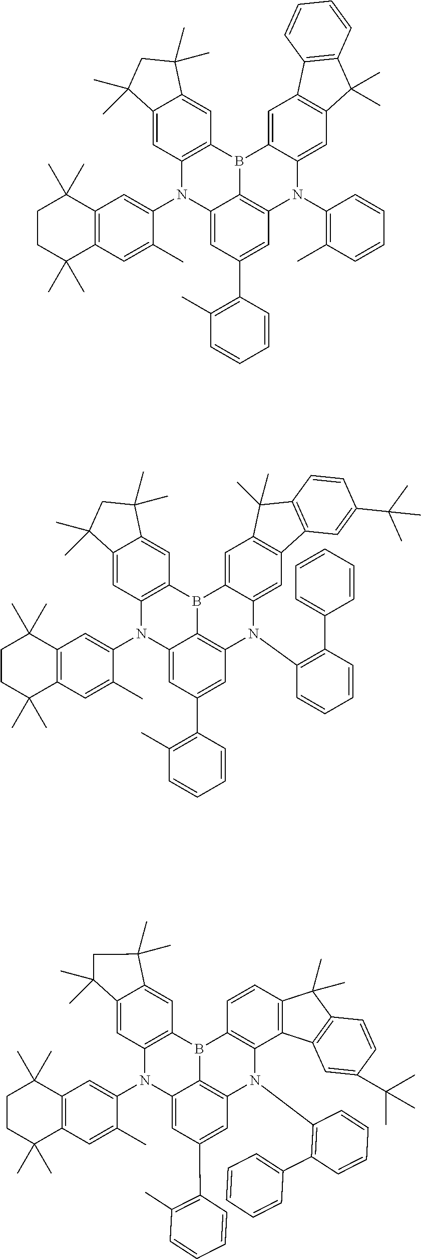 [SMILES: Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)-c1ccccc1C4(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1ccccc1-c1cc2c3c(c1)N(c1ccccc1-c1ccccc1)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C]

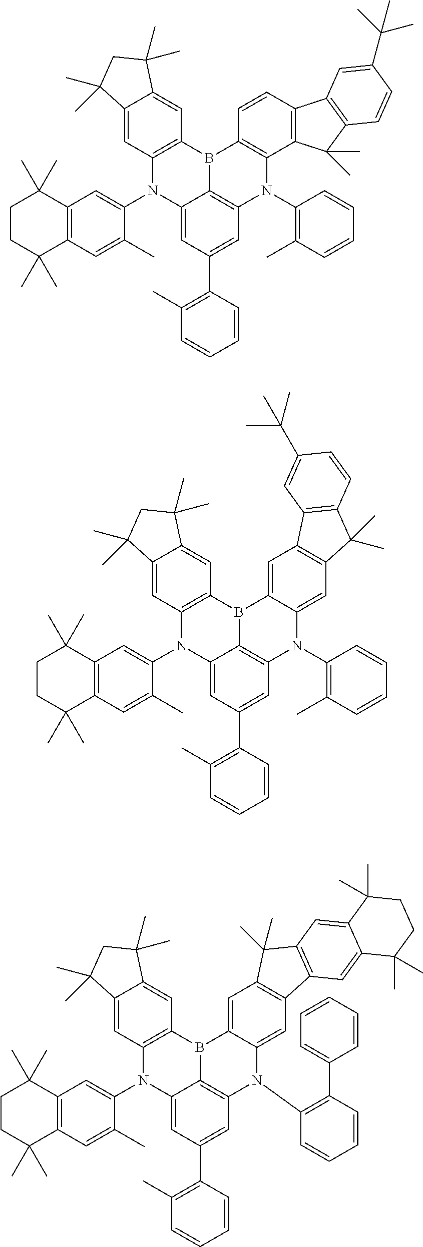 [SMILES: Cc1ccccc1-c1cc2c3c(c1)N(c1ccccc1C)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

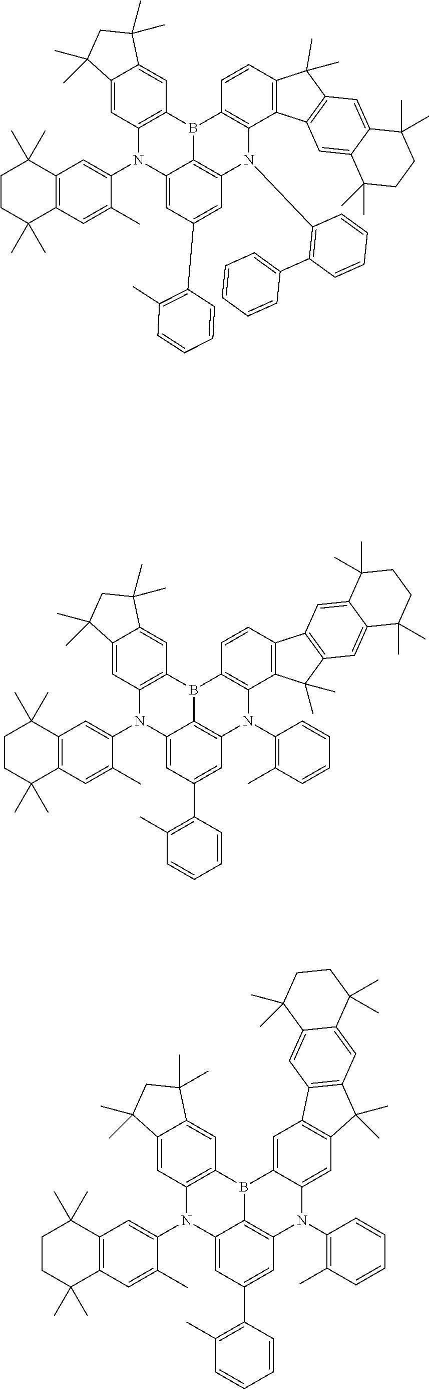 [SMILES: Cc1ccccc1-c1cc2c3c(c1)N(c1ccccc1-c1ccccc1)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C]

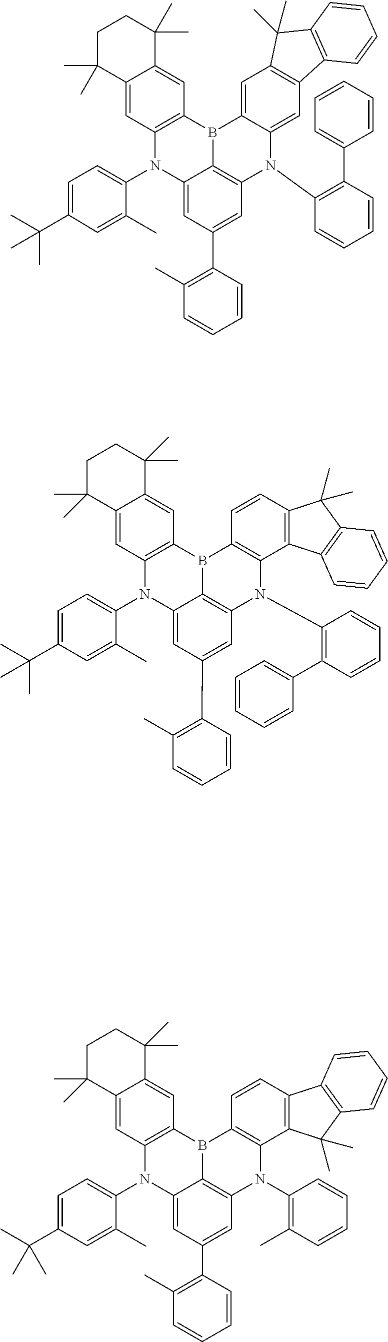 [SMILES: Cc1ccccc1-c1cc2c3c(c1)N(c1ccccc1-c1ccccc1)c1cc4c(cc1B3c1cc3c(cc1N2c1ccc(C(C)(C)C)cc1C)C(C)(C)CCC3(C)C)C(C)(C)c1ccccc1-4 ; Cc1ccccc1-c1cc2c3c(c1)N(c1ccccc1-c1ccccc1)c1c(ccc4c1-c1ccccc1C4(C)C)B3c1cc3c(cc1N2c1ccc(C(C)(C)C)cc1C)C(C)(C)CCC3(C)C ; Cc1ccccc1-c1cc2c3c(c1)N(c1ccccc1C)c1c(ccc4c1C(C)(C)c1ccccc1-4)B3c1cc3c(cc1N2c1ccc(C(C)(C)C)cc1C)C(C)(C)CCC3(C)C]

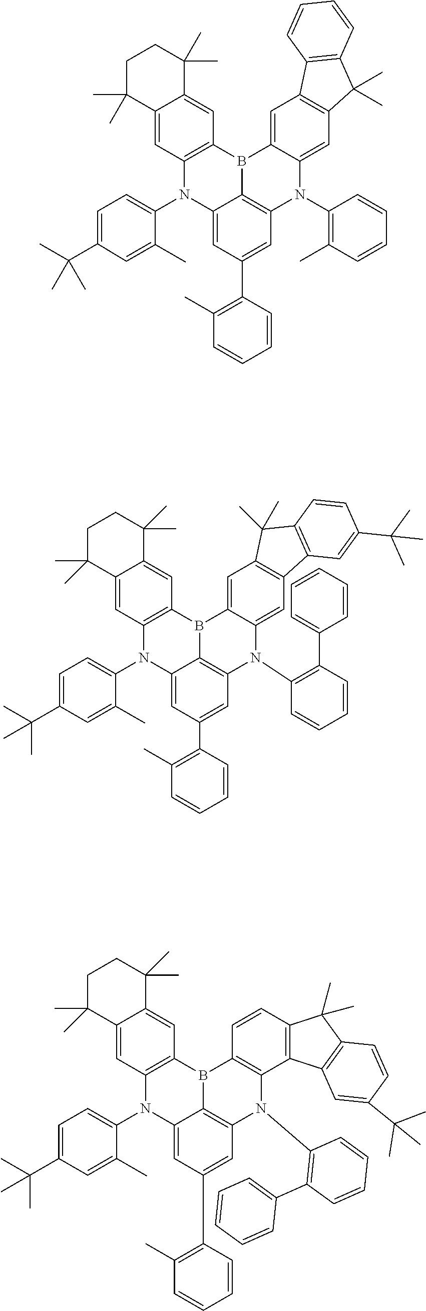

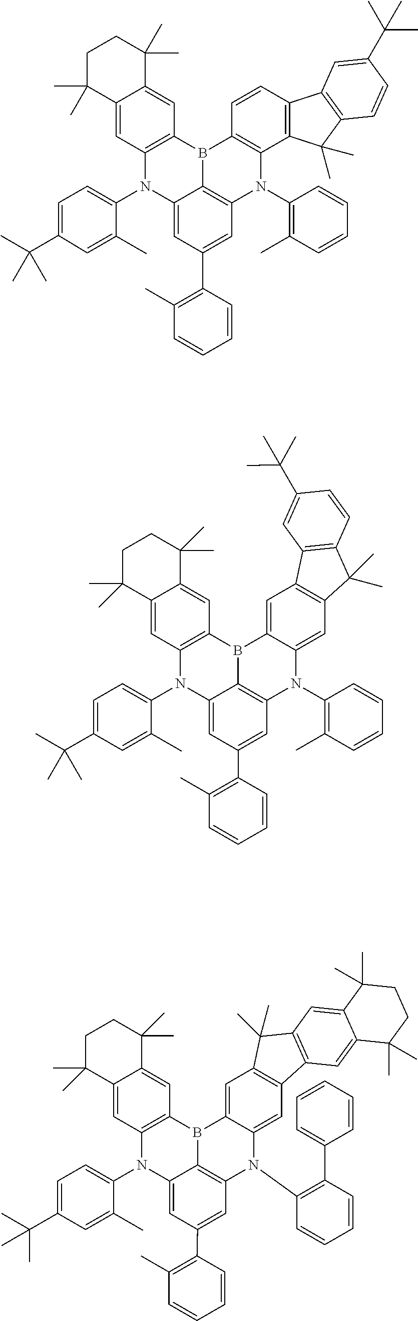

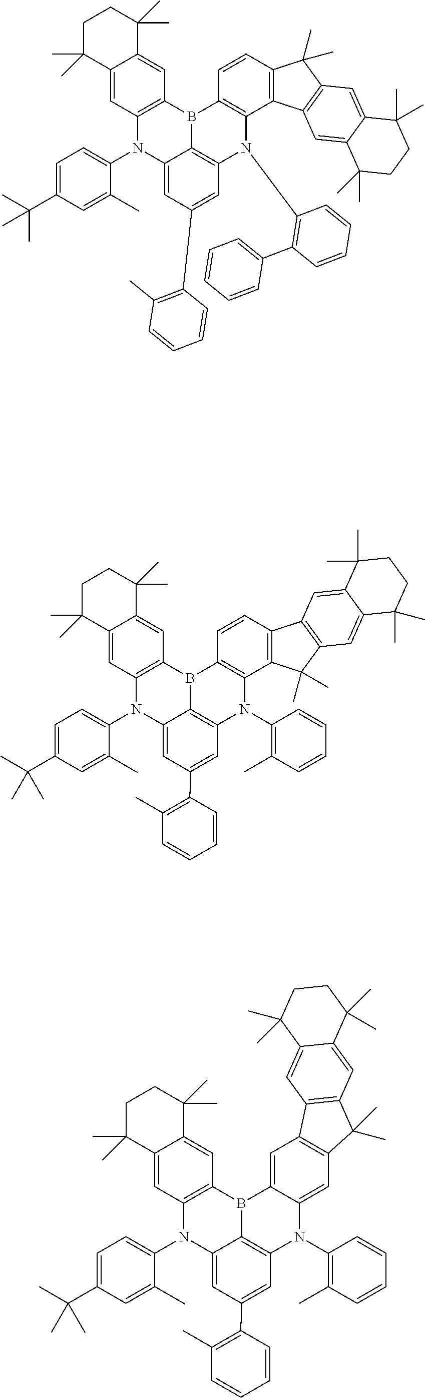

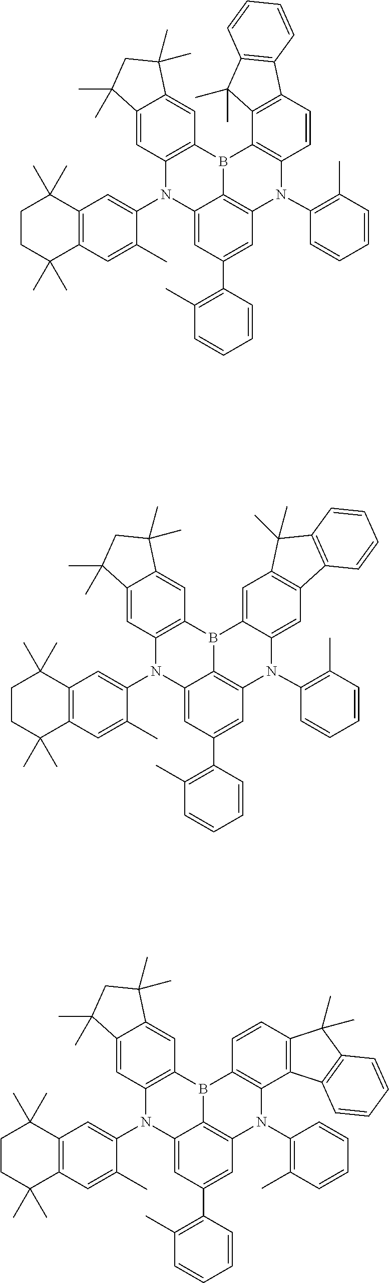 [SMILES: Cc1ccccc1-c1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1ccccc1-4 ; Cc1ccccc1-c1cc2c3c(c1)N(c1cc4c(cc1C)C(C)(C)CCC4(C)C)c1cc4c(cc1B3c1cc3c(cc1N2c1ccccc1C)-c1ccccc1C3(C)C)C(C)(C)CC4(C)C ; Cc1ccccc1-c1cc2c3c(c1)N(c1ccccc1C)c1c(ccc4c1-c1ccccc1C4(C)C)B3c1cc3c(cc1N2c1cc2c(cc1C)C(C)(C)CCC2(C)C)C(C)(C)CC3(C)C]

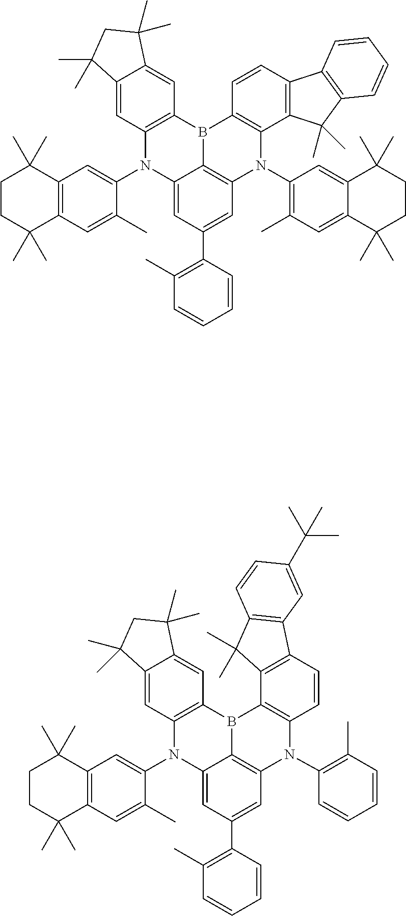 [SMILES: Cc1ccccc1-c1cc2c3c(c1)N(c1cc4c(cc1C)C(C)(C)CCC4(C)C)c1c(ccc4c1C(C)(C)c1ccccc1-4)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4]

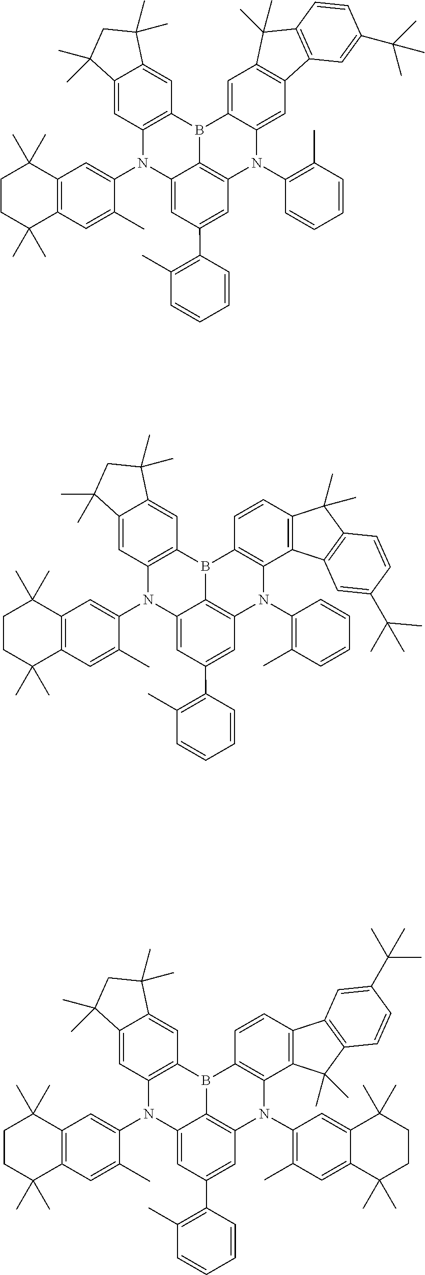 [SMILES: Cc1ccccc1-c1cc2c3c(c1)N(c1cc4c(cc1C)C(C)(C)CCC4(C)C)c1cc4c(cc1B3c1cc3c(cc1N2c1ccccc1C)-c1cc(C(C)(C)C)ccc1C3(C)C)C(C)(C)CC4(C)C ; Cc1ccccc1-c1cc2c3c(c1)N(c1ccccc1C)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C]

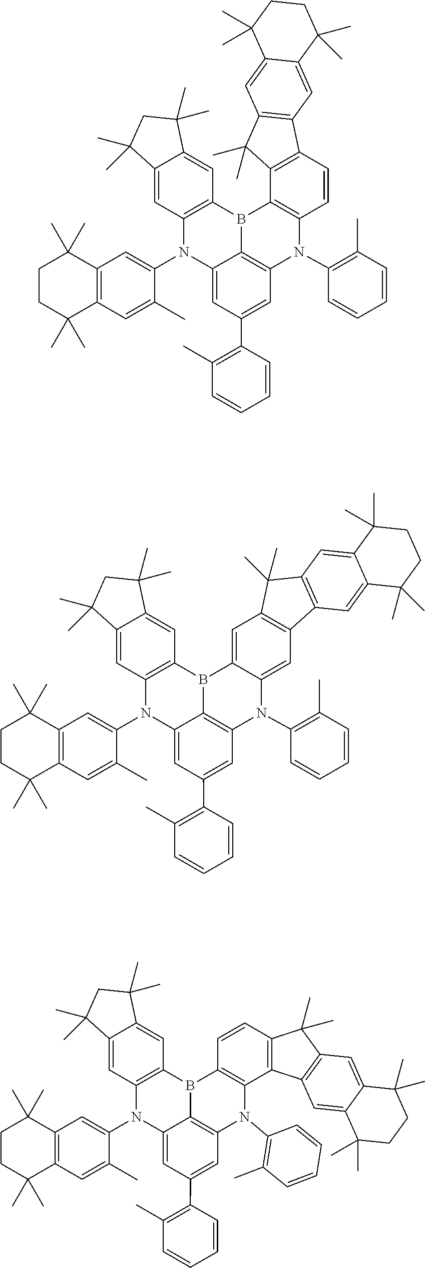 [SMILES: Cc1ccccc1-c1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1ccccc1-c1cc2c3c(c1)N(c1cc4c(cc1C)C(C)(C)CCC4(C)C)c1cc4c(cc1B3c1cc3c(cc1N2c1ccccc1C)-c1cc2c(cc1C3(C)C)C(C)(C)CCC2(C)C)C(C)(C)CC4(C)C ; Cc1ccccc1-c1cc2c3c(c1)N(c1ccccc1C)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C]

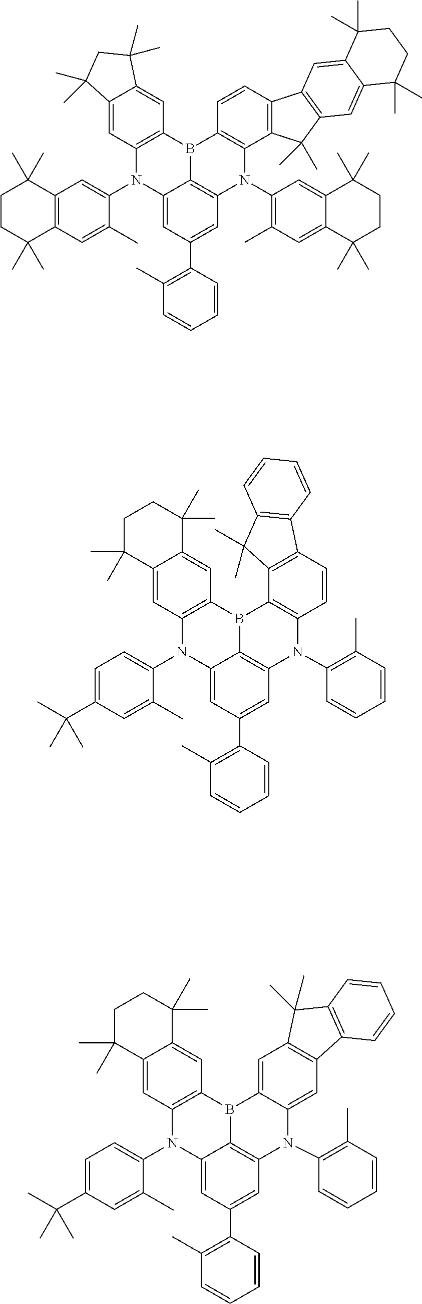

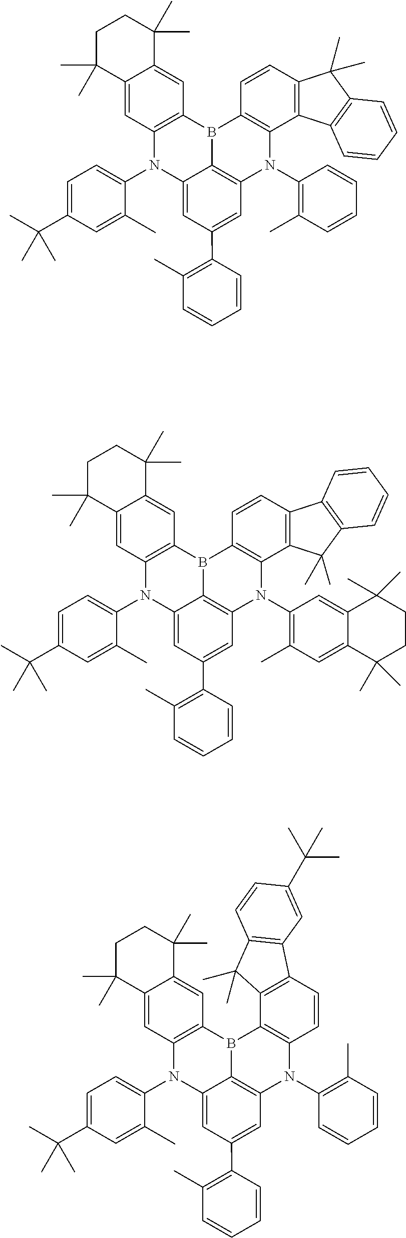 [SMILES: Cc1ccccc1-c1cc2c3c(c1)N(c1ccccc1C)c1c(ccc4c1-c1ccccc1C4(C)C)B3c1cc3c(cc1N2c1ccc(C(C)(C)C)cc1C)C(C)(C)CCC3(C)C ; Cc1ccccc1-c1cc2c3c(c1)N(c1cc4c(cc1C)C(C)(C)CCC4(C)C)c1c(ccc4c1C(C)(C)c1ccccc1-4)B3c1cc3c(cc1N2c1ccc(C(C)(C)C)cc1C)C(C)(C)CCC3(C)C ; Cc1ccccc1-c1cc2c3c(c1)N(c1ccccc1C)c1ccc4c(c1B3c1cc3c(cc1N2c1ccc(C(C)(C)C)cc1C)C(C)(C)CCC3(C)C)C(C)(C)c1ccc(C(C)(C)C)cc1-4]

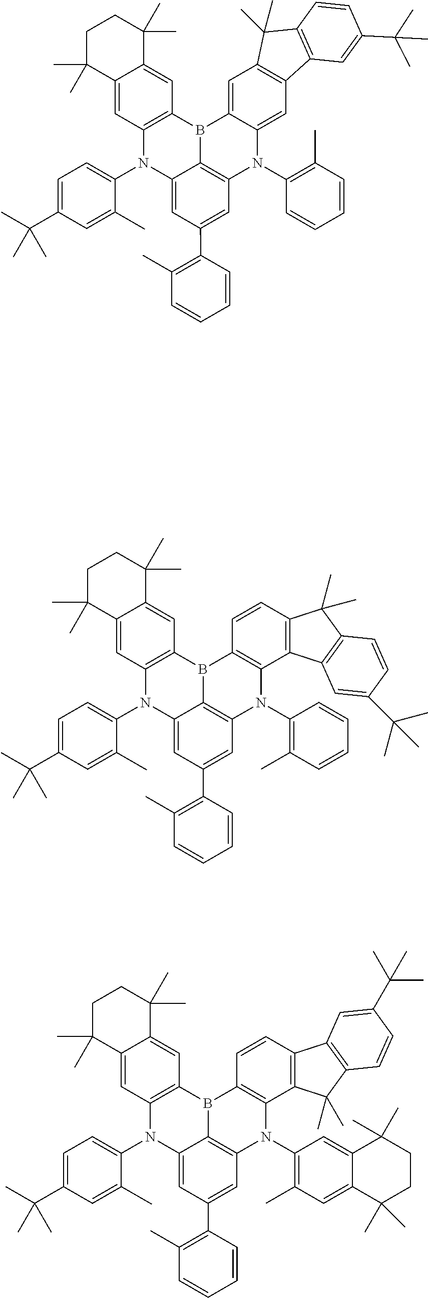

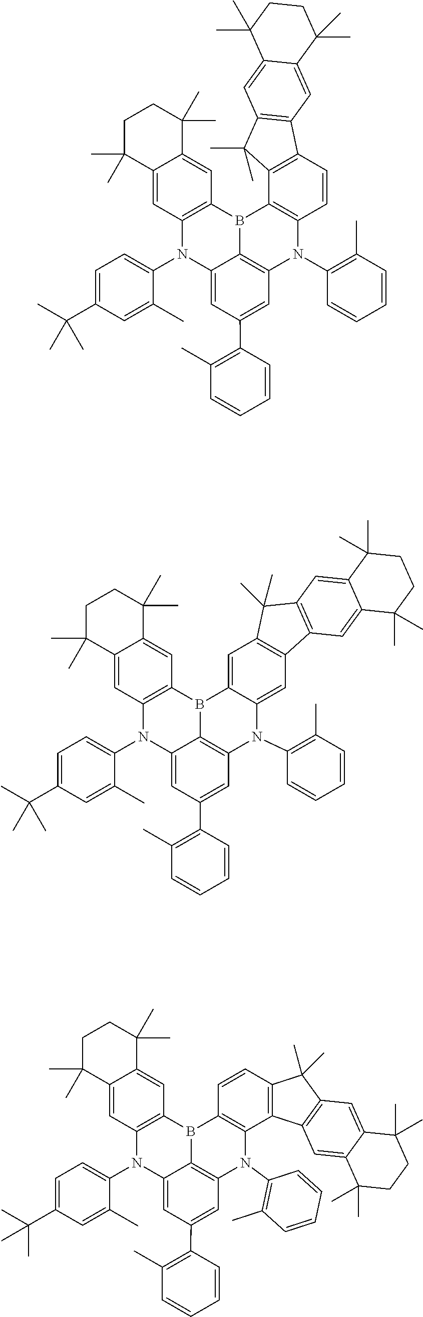

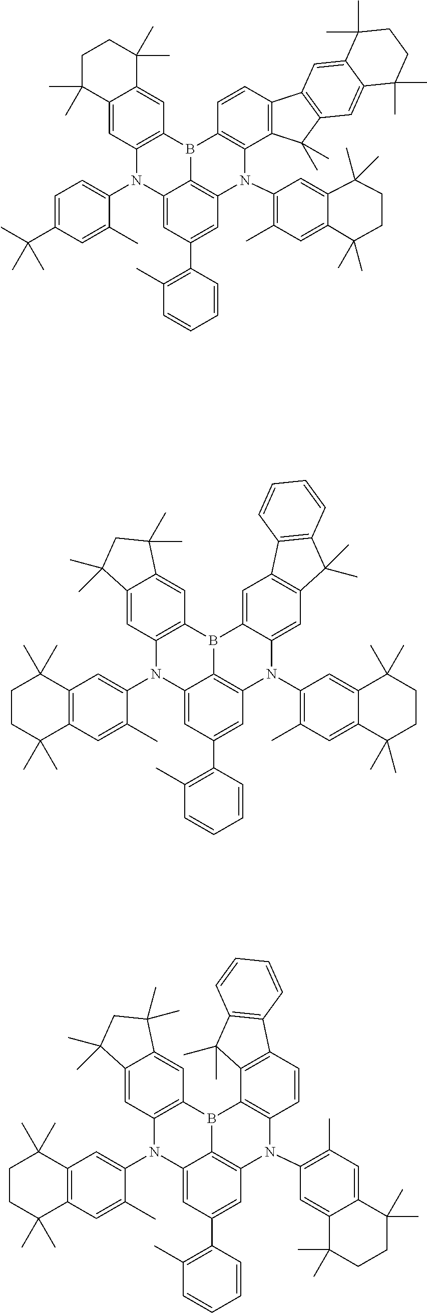 [SMILES: Cc1ccccc1-c1cc2c3c(c1)N(c1cc4c(cc1C)C(C)(C)CCC4(C)C)c1c(ccc4c1C(C)(C)c1cc5c(cc1-4)C(C)(C)CCC5(C)C)B3c1cc3c(cc1N2c1ccc(C(C)(C)C)cc1C)C(C)(C)CCC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1ccccc1C4(C)C ; Cc1ccccc1-c1cc2c3c(c1)N(c1cc4c(cc1C)C(C)(C)CCC4(C)C)c1ccc4c(c1B3c1cc3c(cc1N2c1cc2c(cc1C)C(C)(C)CCC2(C)C)C(C)(C)CC3(C)C)C(C)(C)c1ccccc1-4]

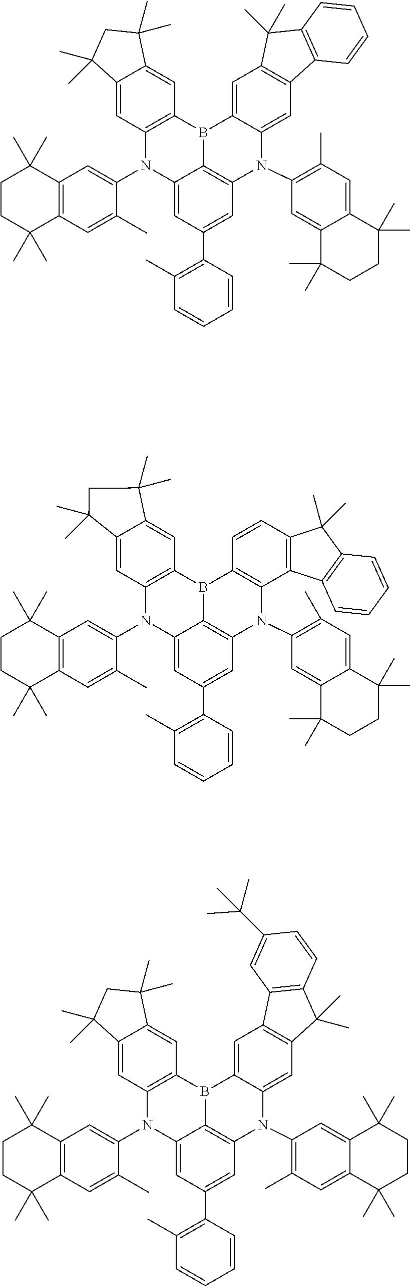 [SMILES: Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)-c1ccccc1C3(C)C)C(C)(C)CC4(C)C ; Cc1ccccc1-c1cc2c3c(c1)N(c1cc4c(cc1C)C(C)(C)CCC4(C)C)c1c(ccc4c1-c1ccccc1C4(C)C)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C]

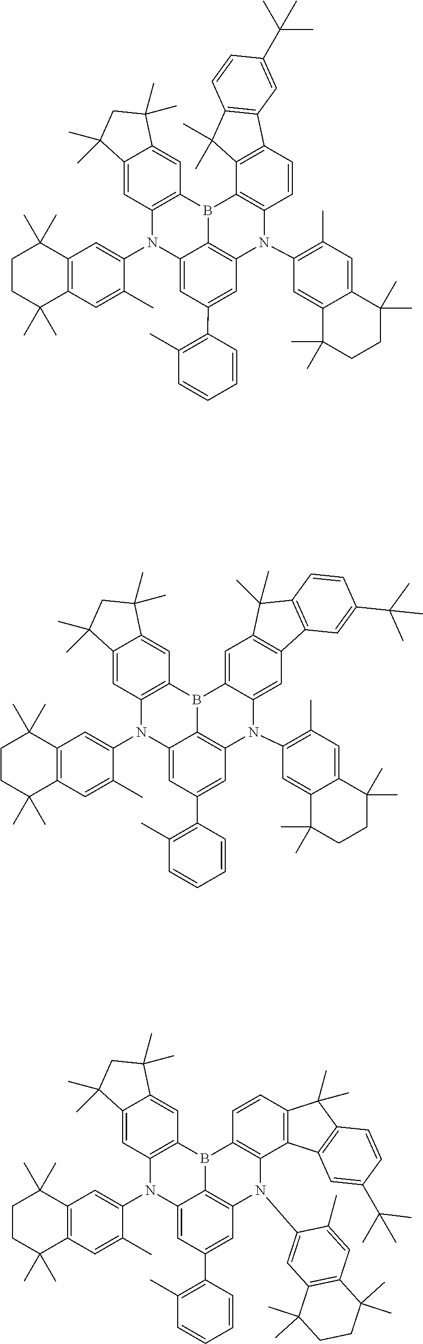 [SMILES: Cc1ccccc1-c1cc2c3c(c1)N(c1cc4c(cc1C)C(C)(C)CCC4(C)C)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)-c1cc(C(C)(C)C)ccc1C3(C)C)C(C)(C)CC4(C)C ; Cc1ccccc1-c1cc2c3c(c1)N(c1cc4c(cc1C)C(C)(C)CCC4(C)C)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C]

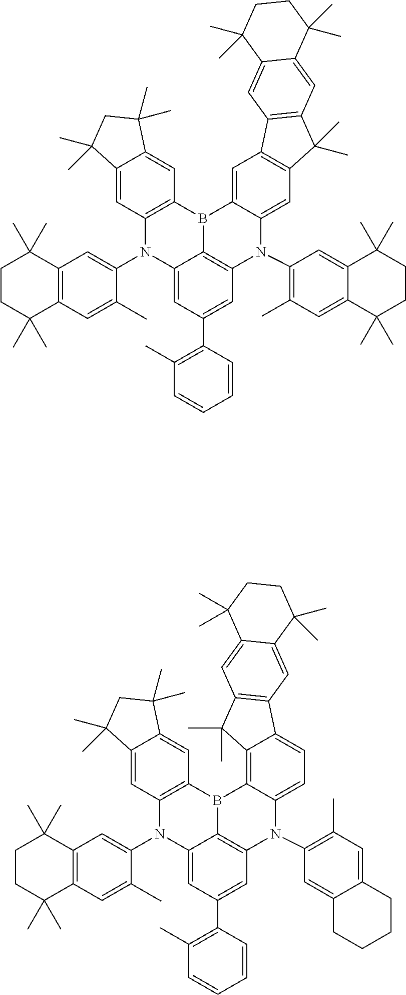 [SMILES: Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1ccccc1-c1cc2c3c(c1)N(c1cc4c(cc1C)CCCC4)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

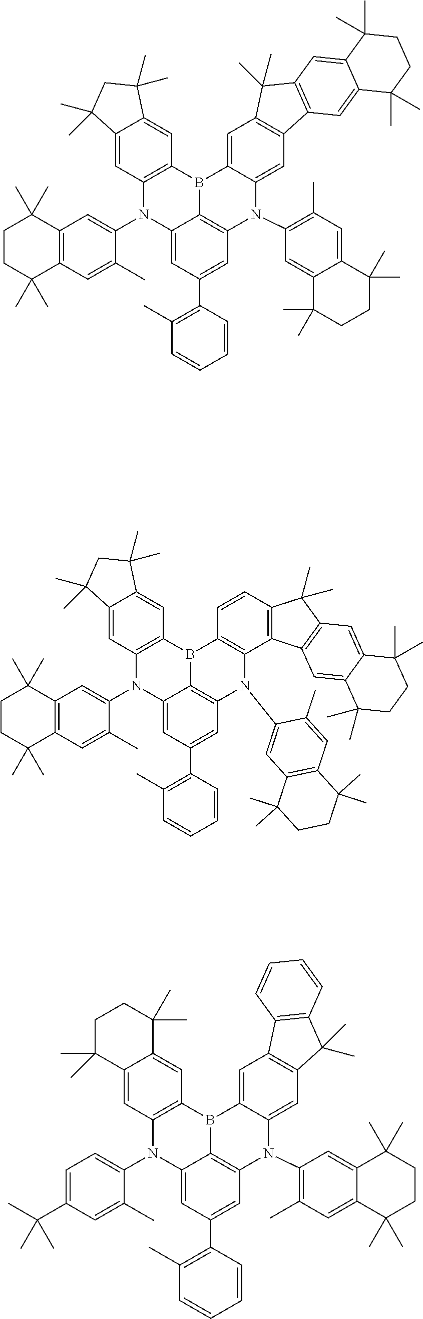

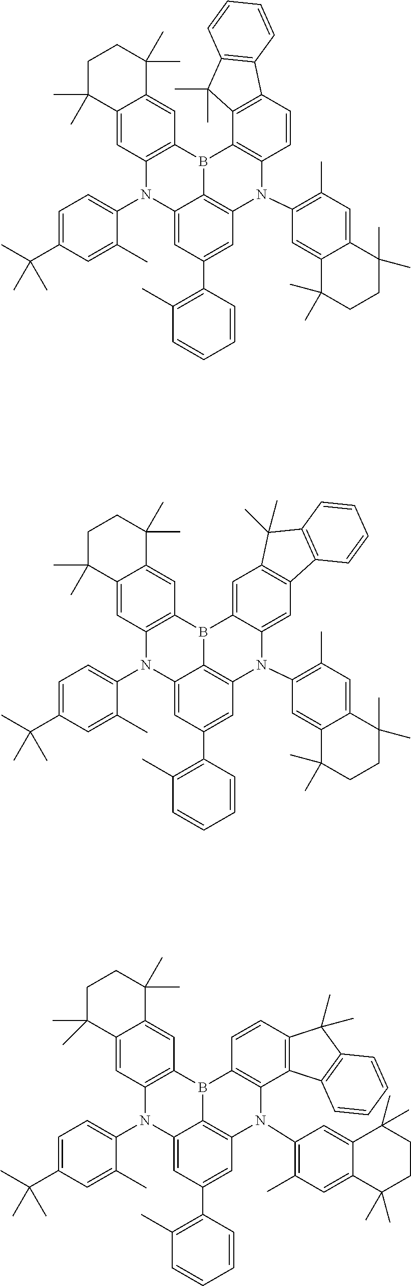

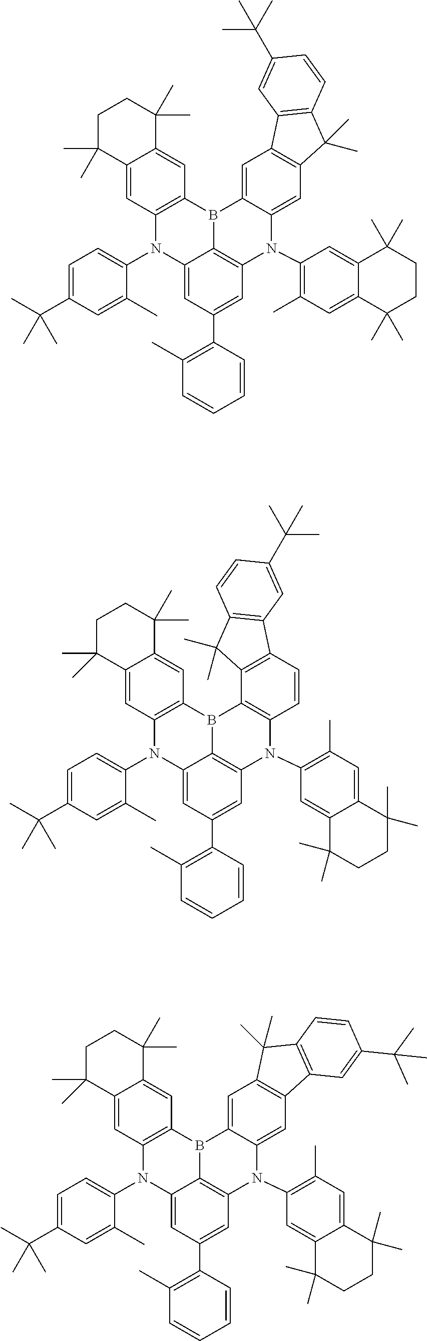

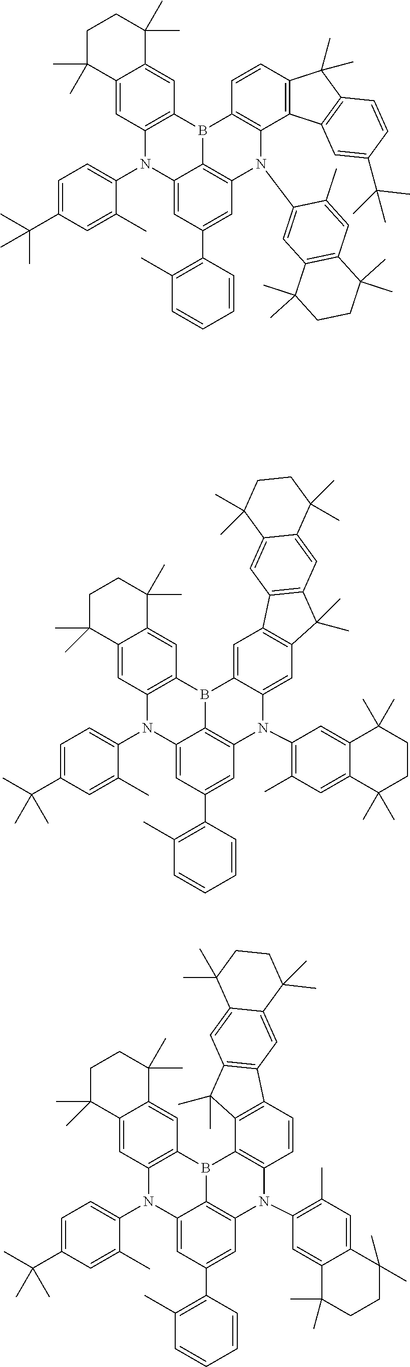

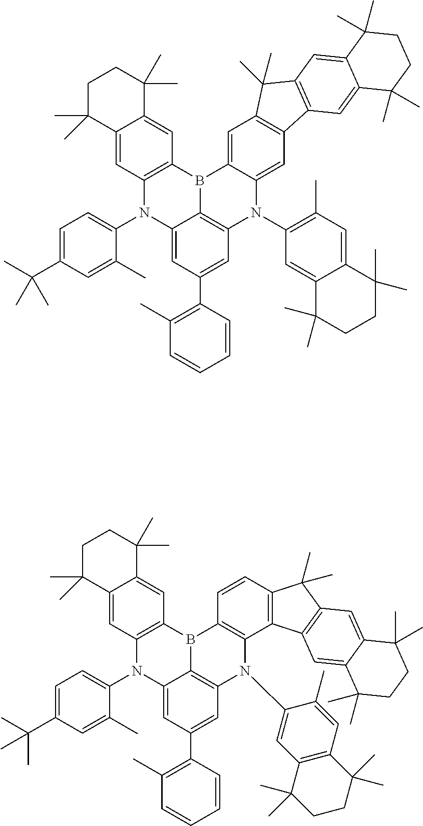

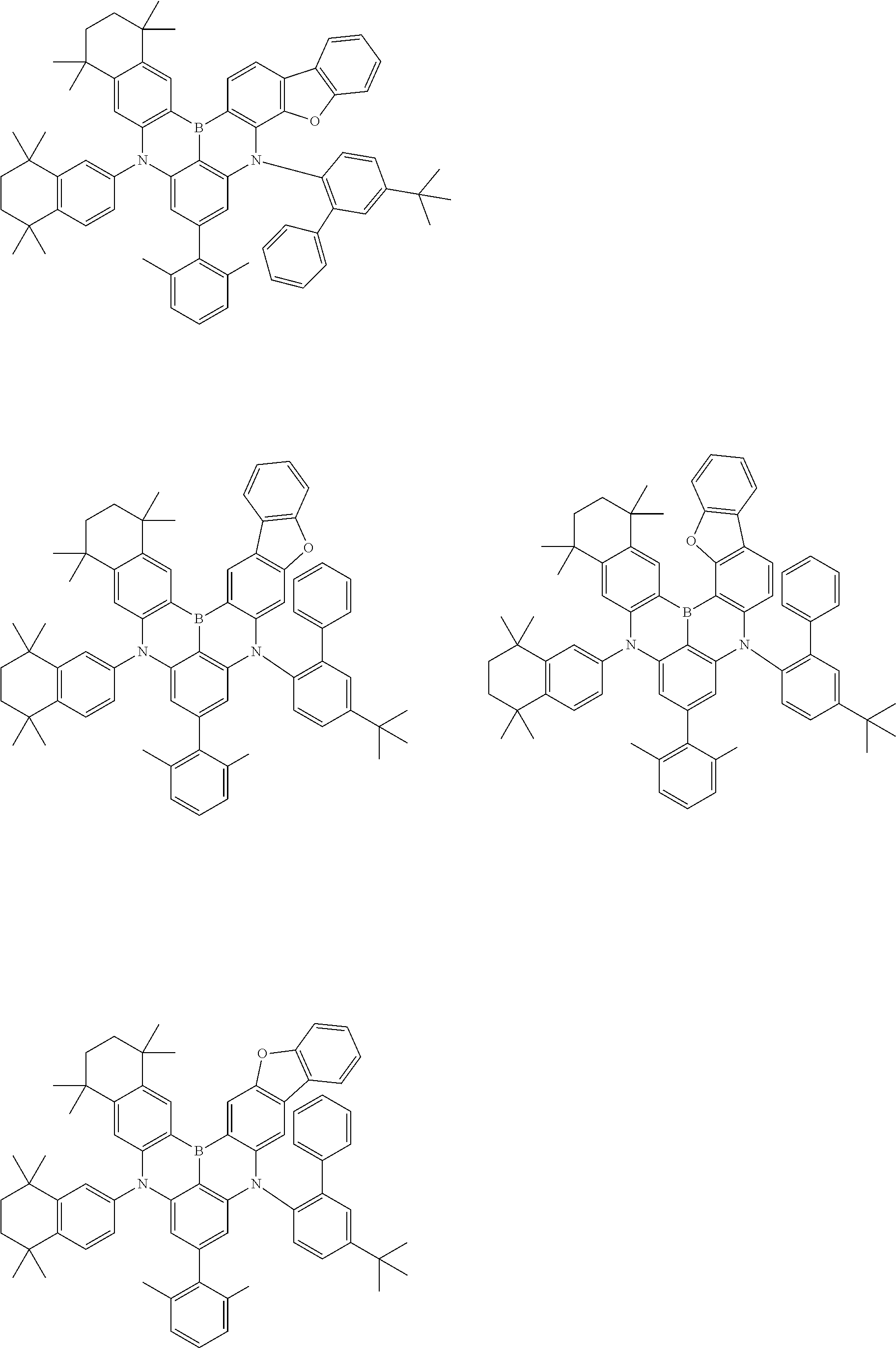

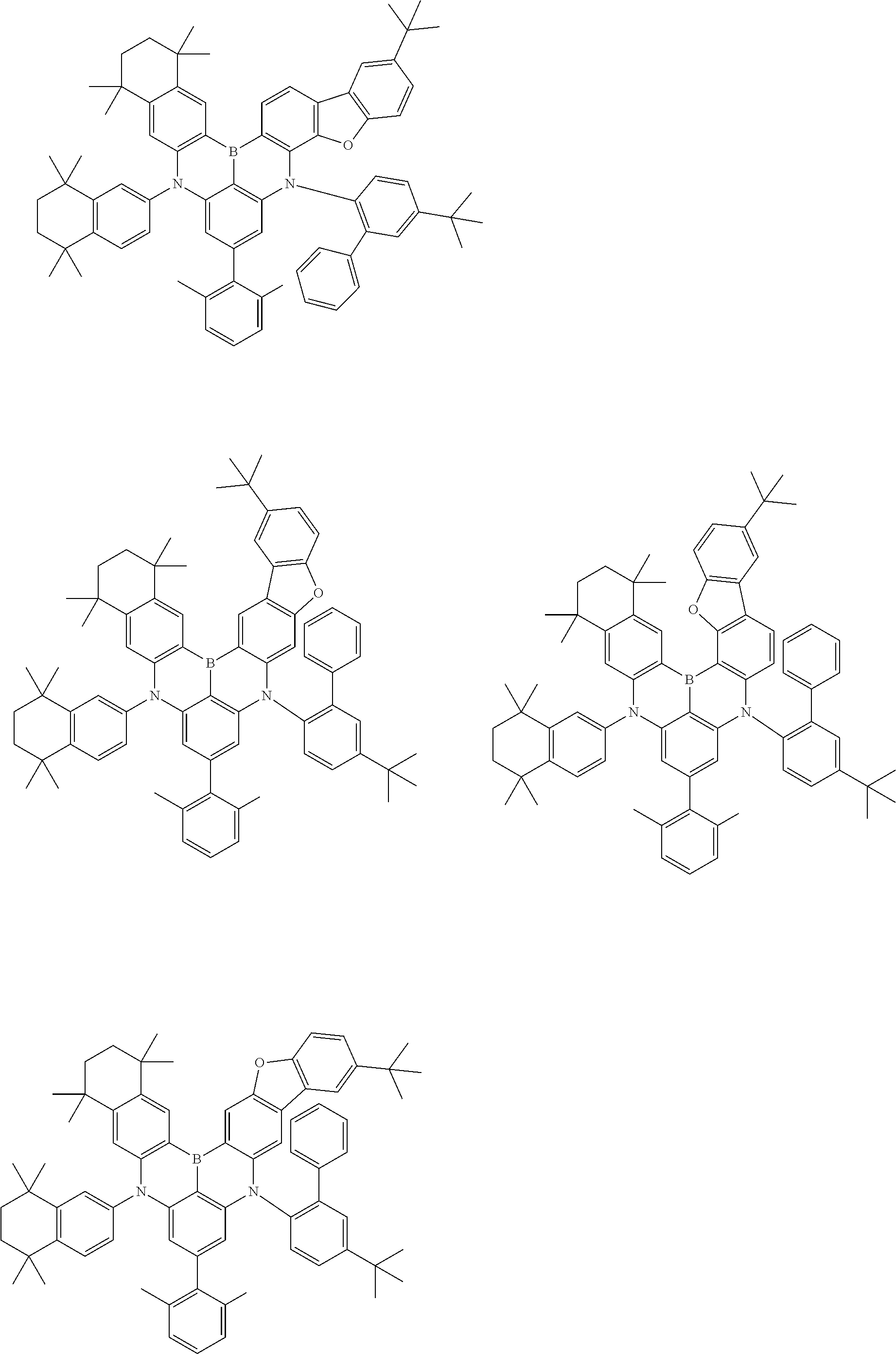

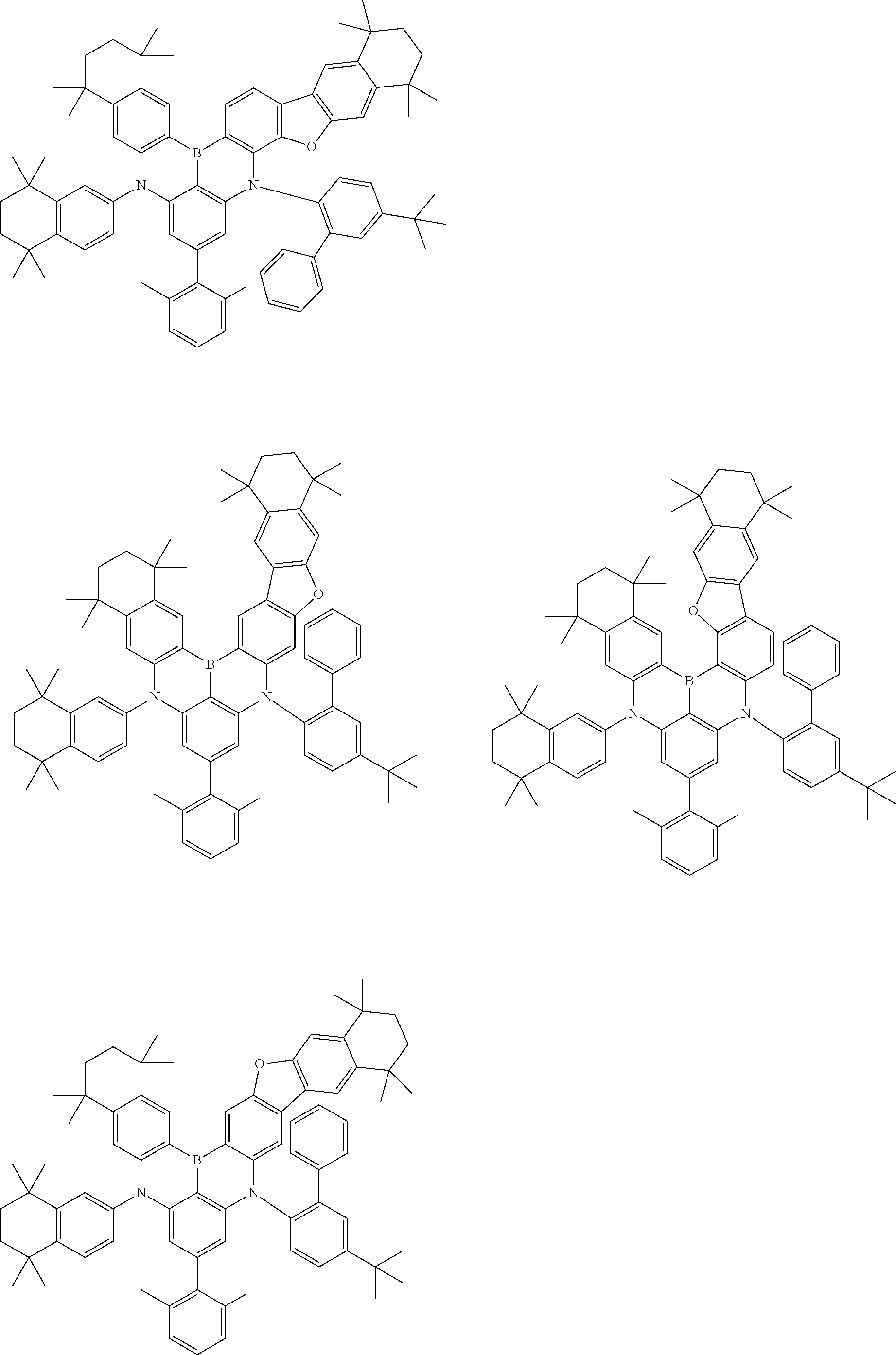

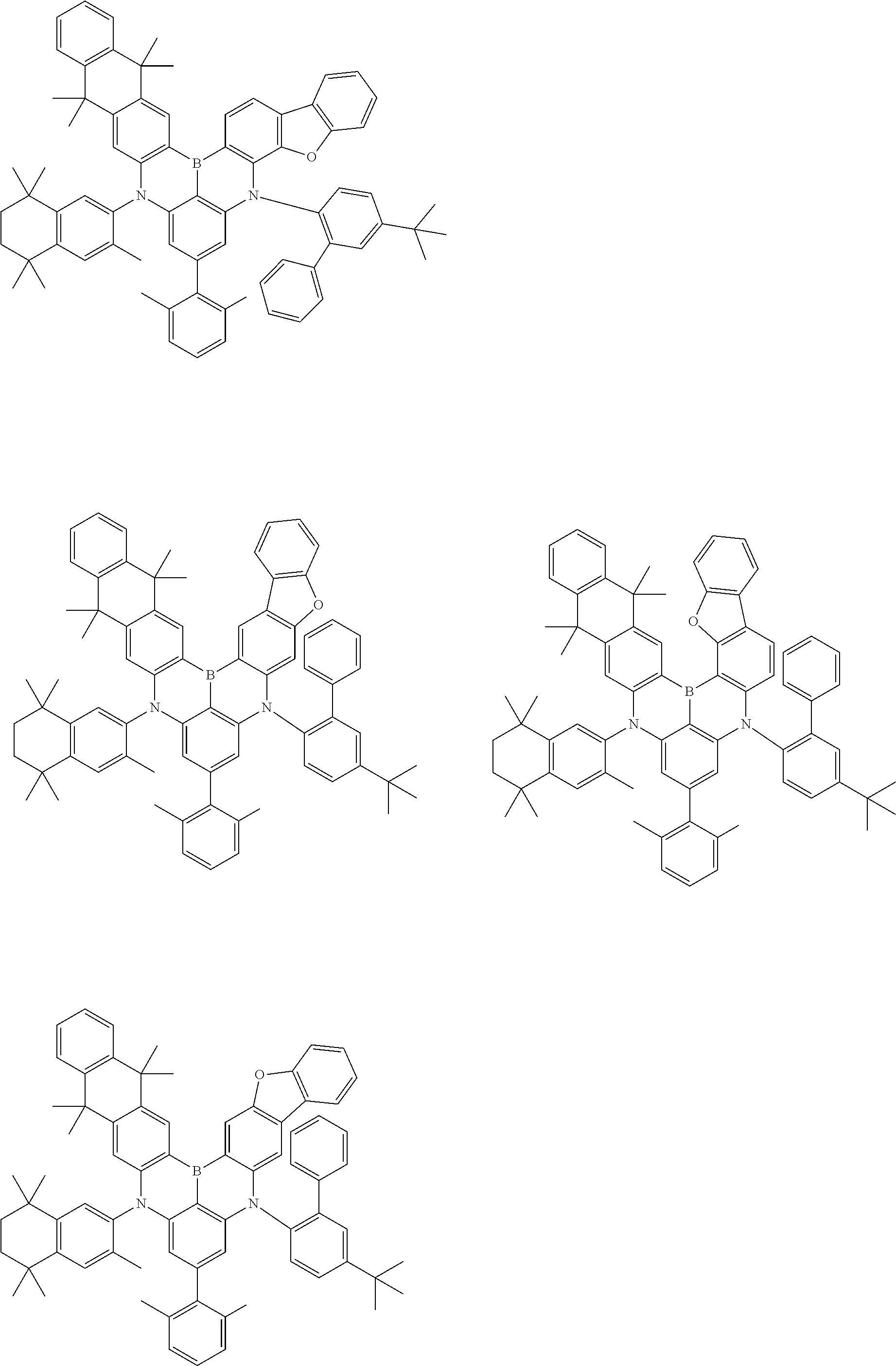

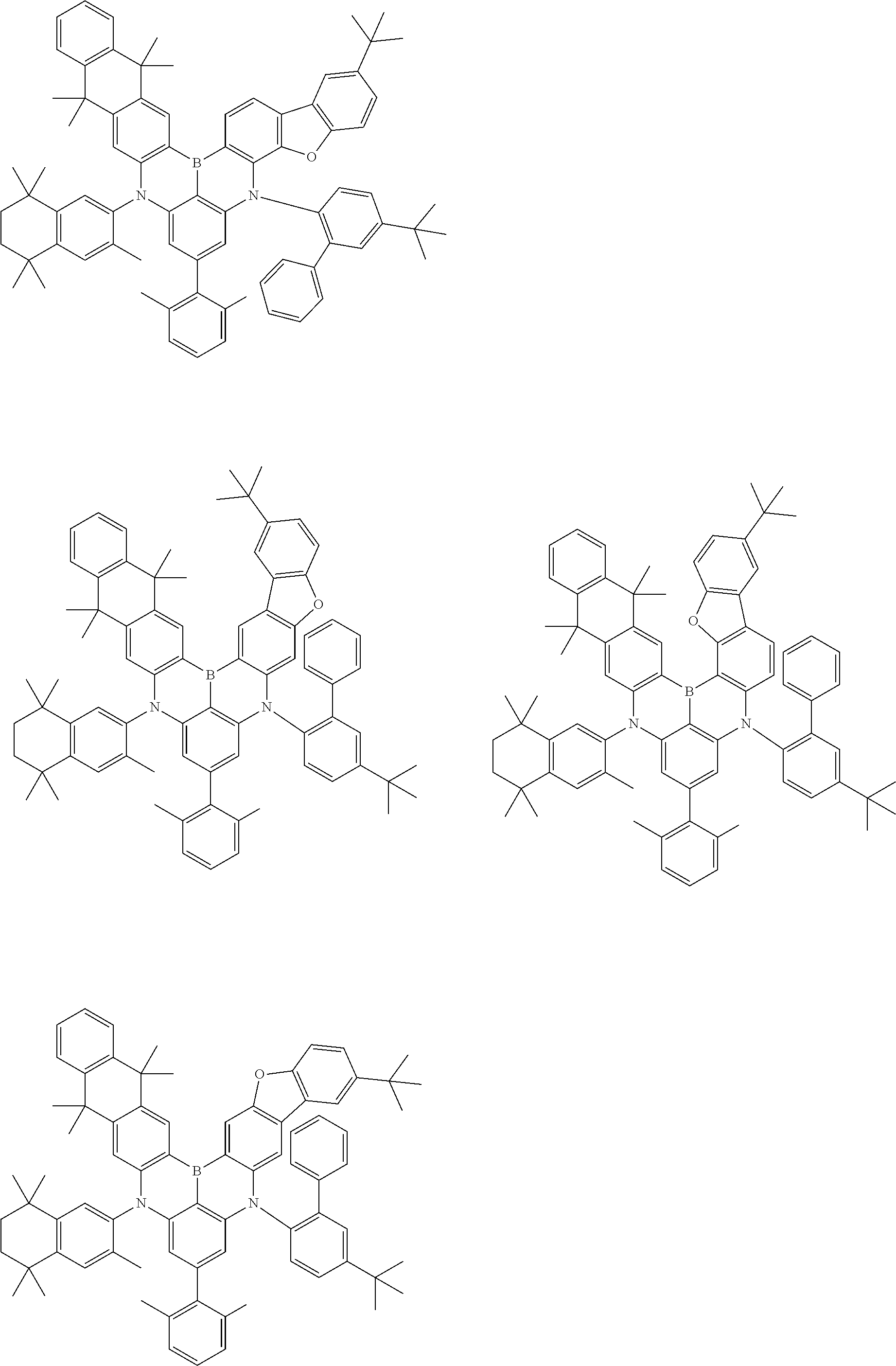

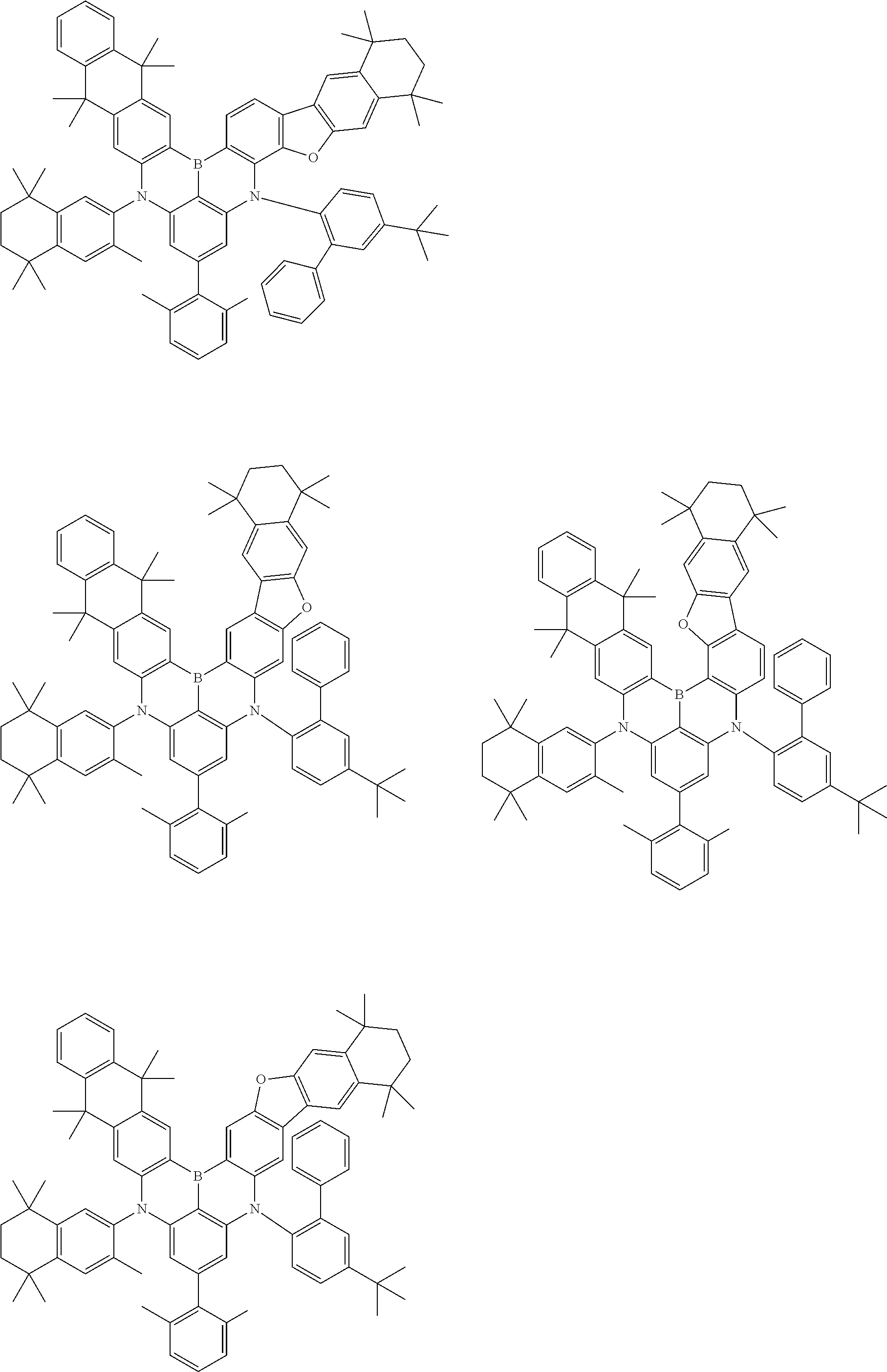

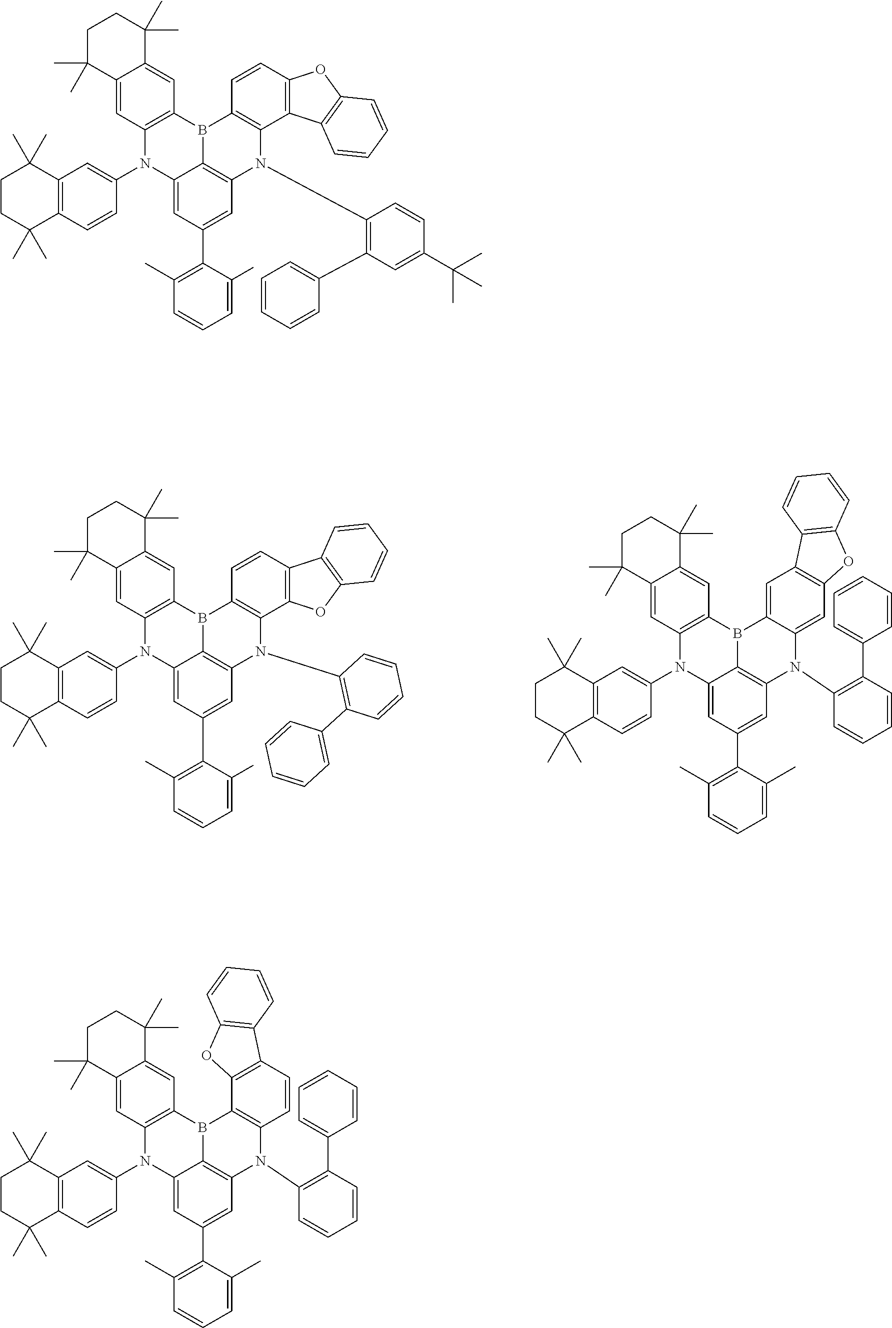

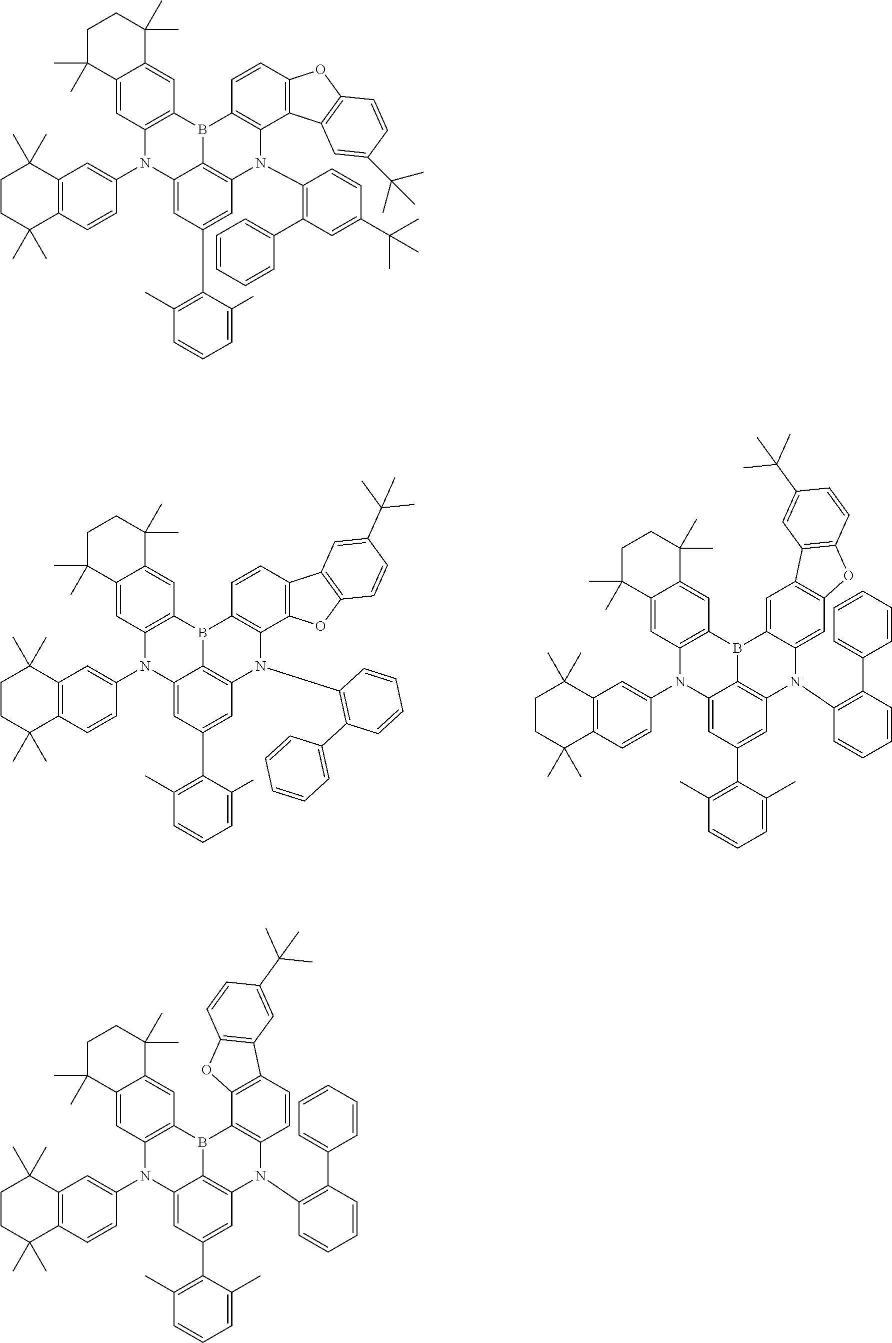

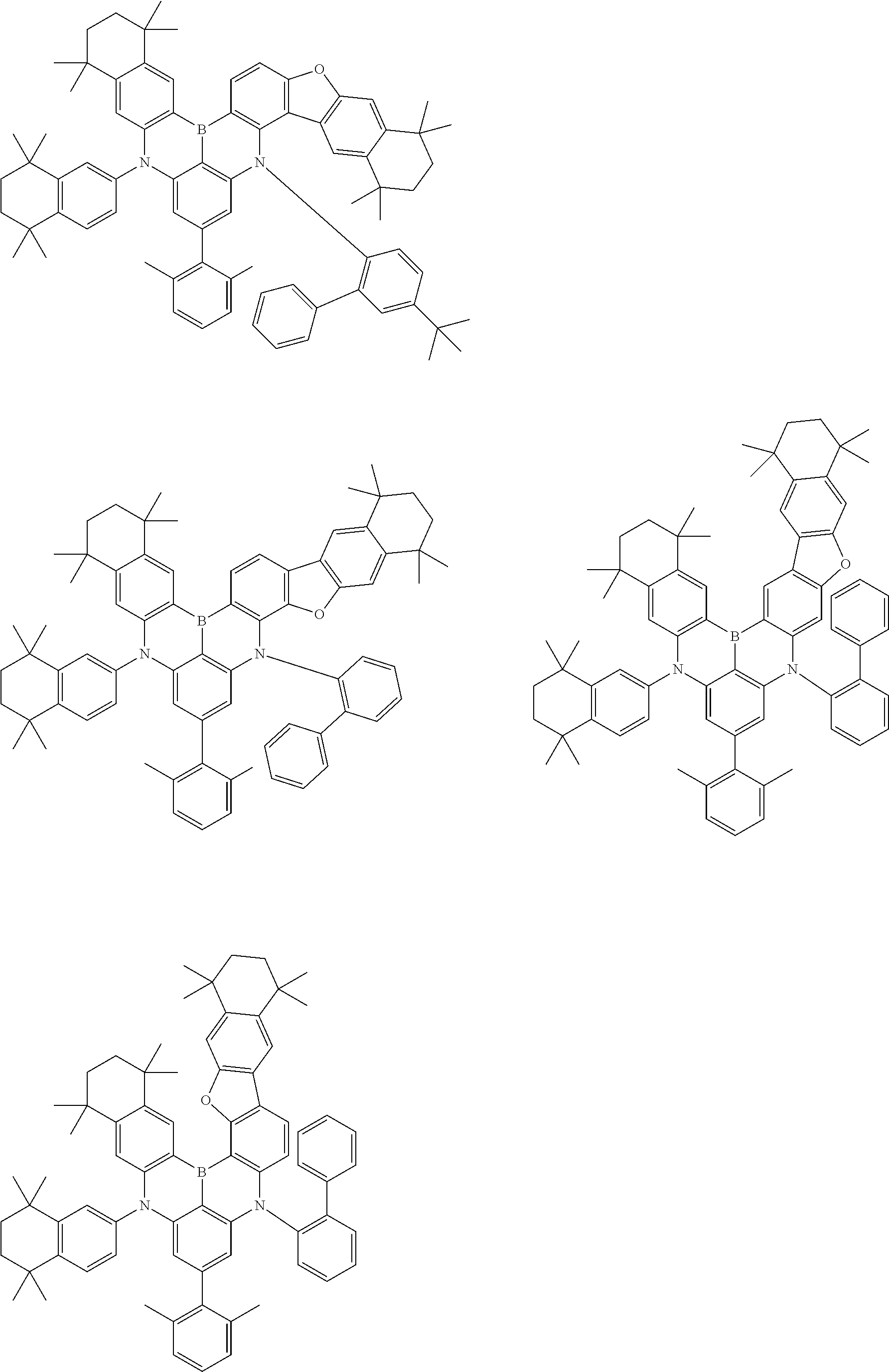

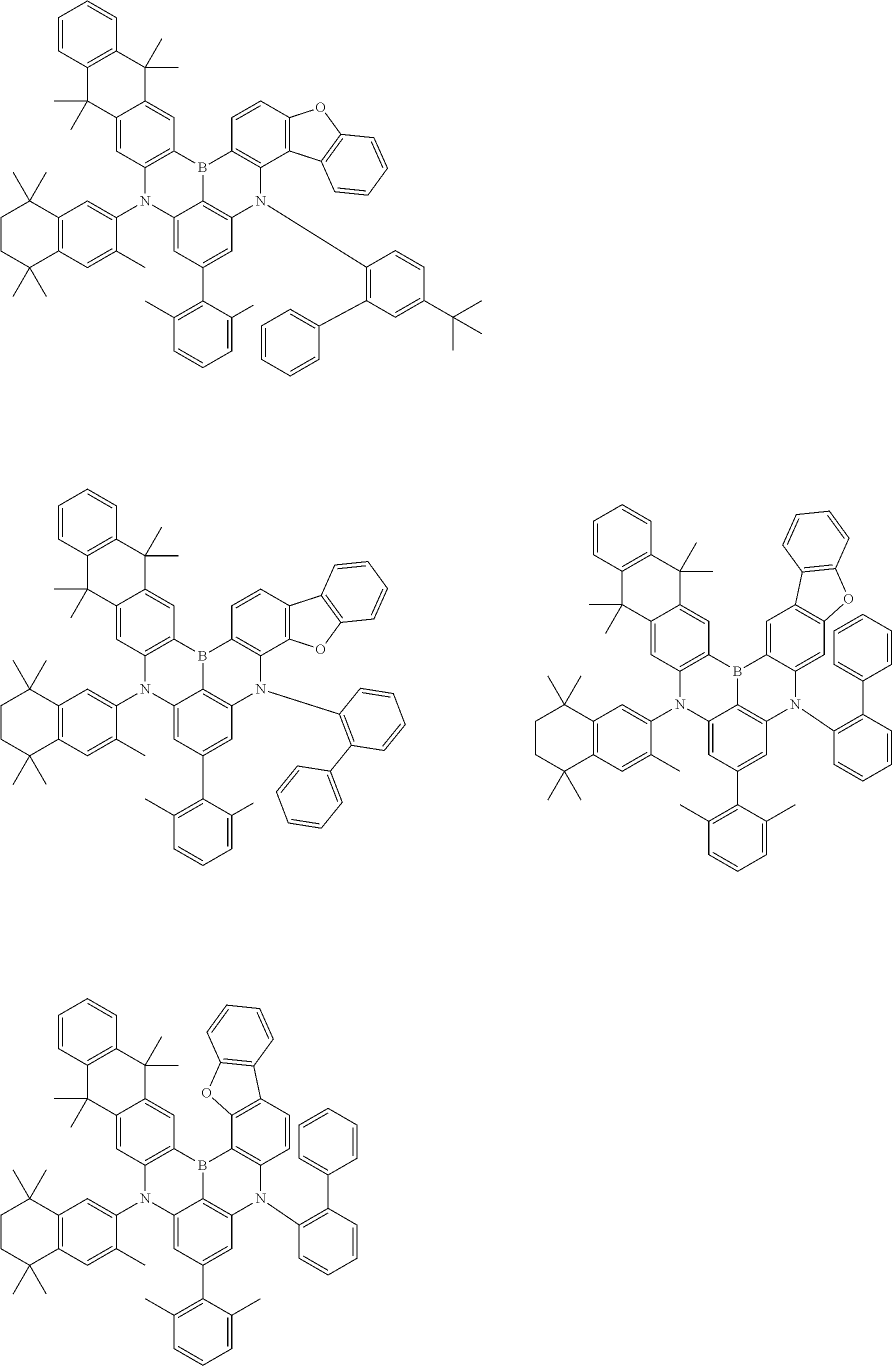

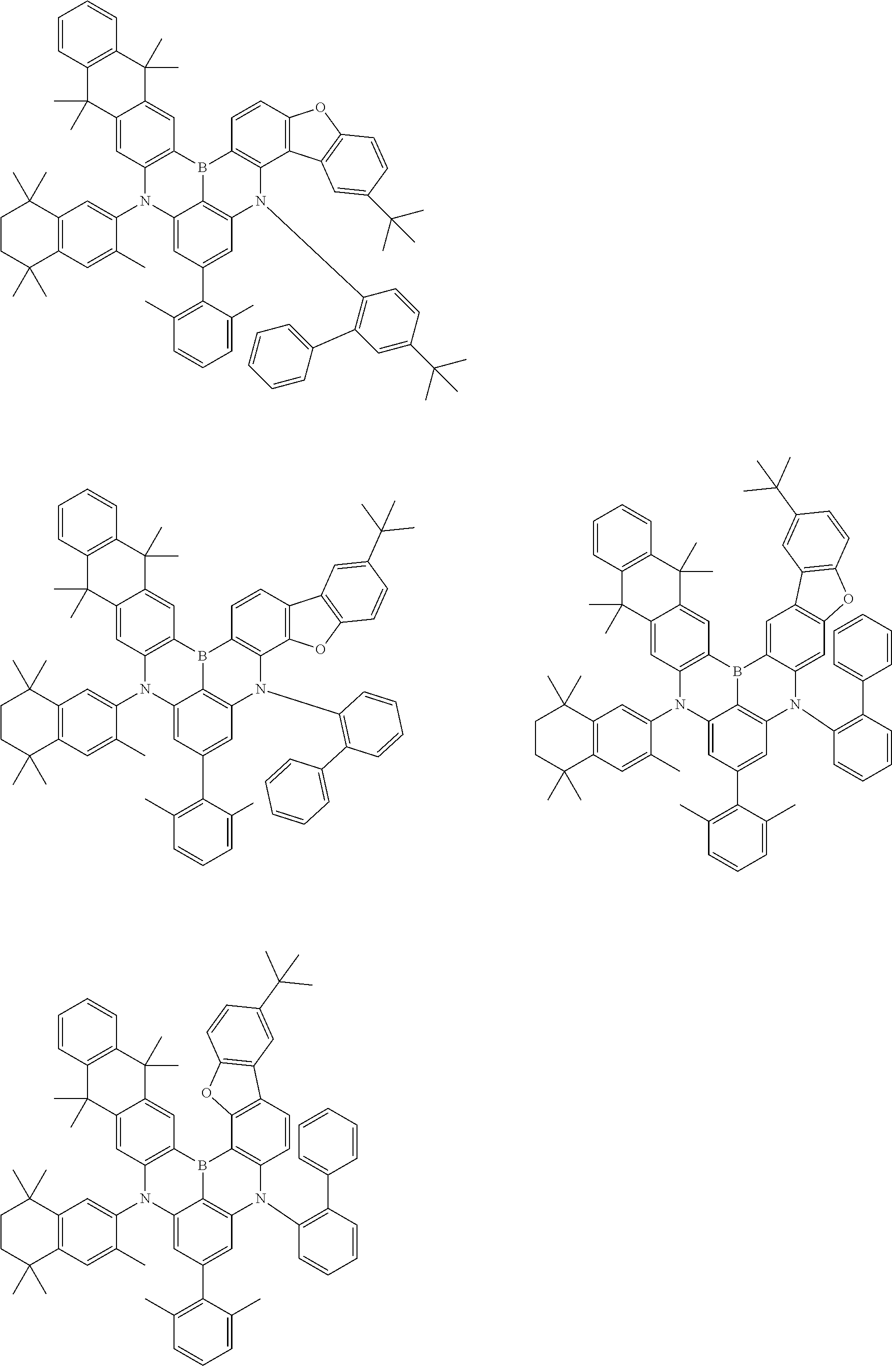

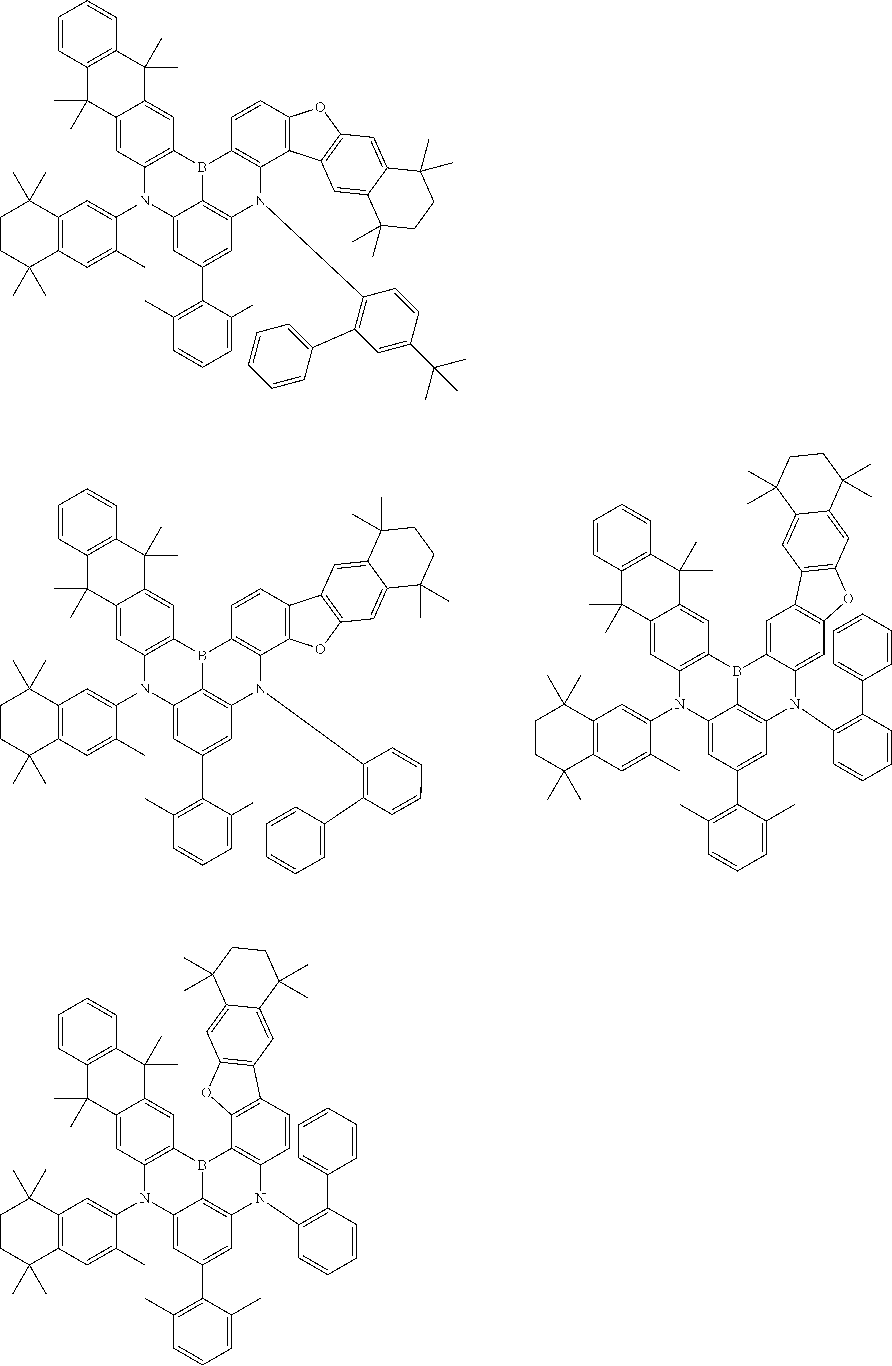

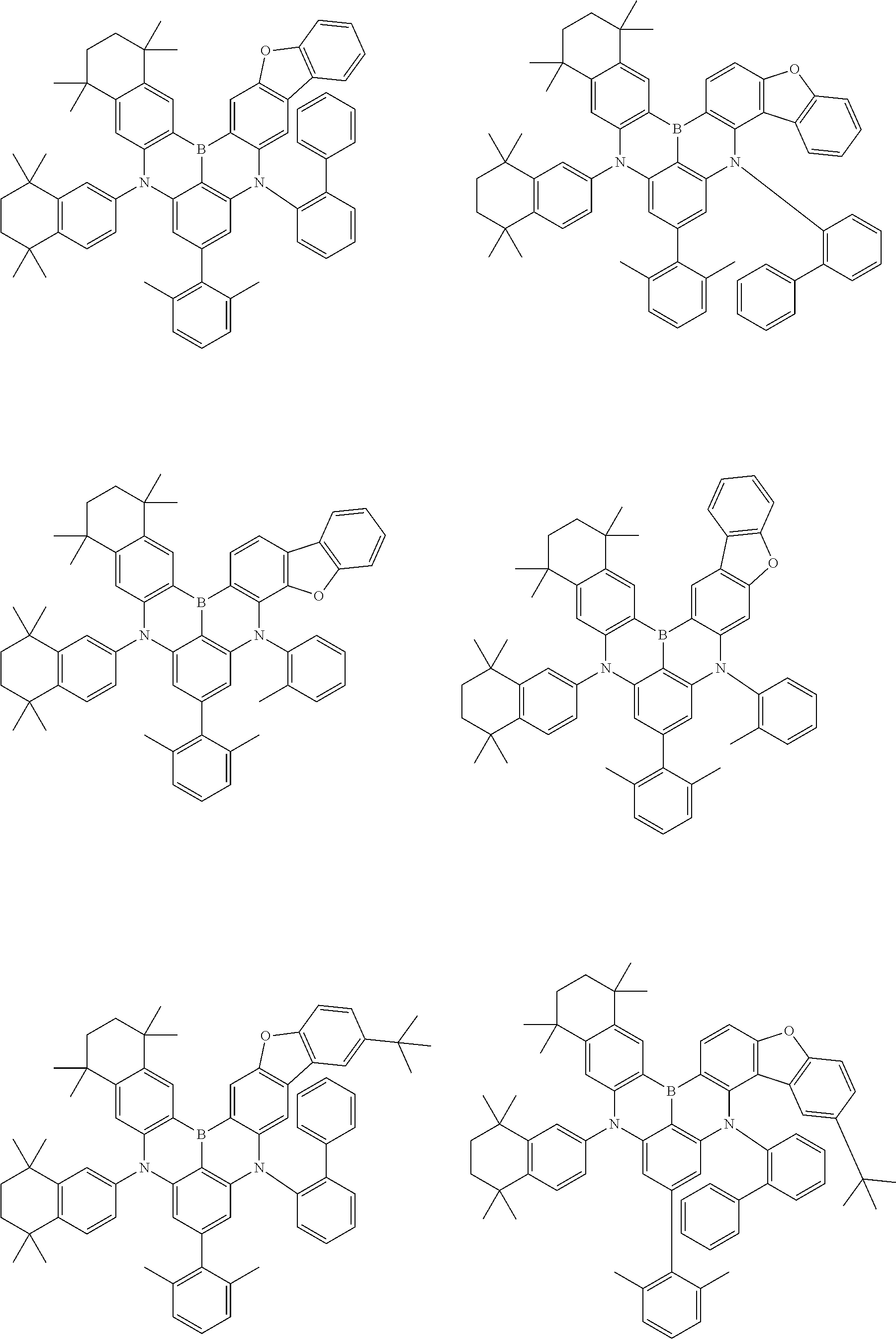

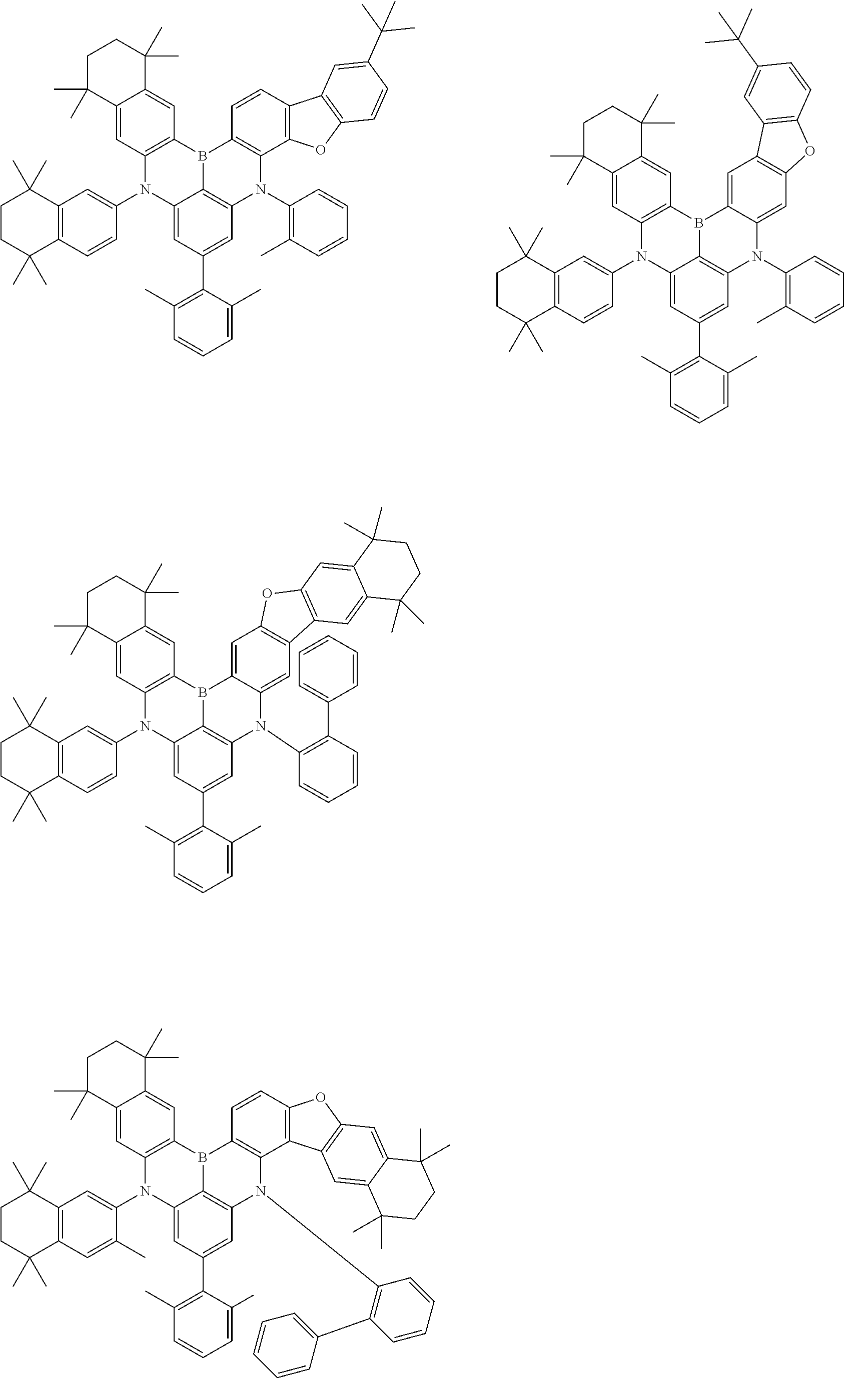

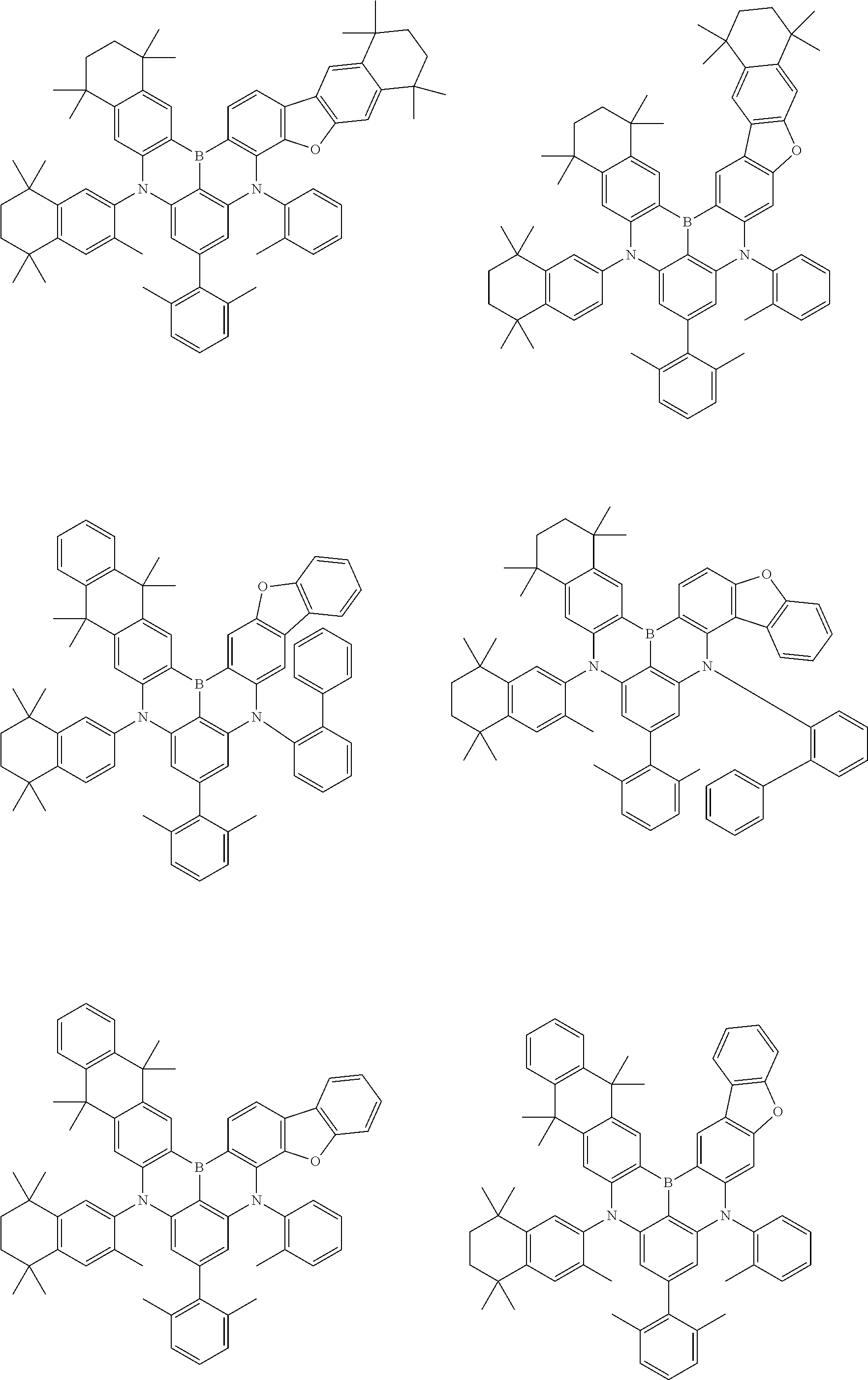

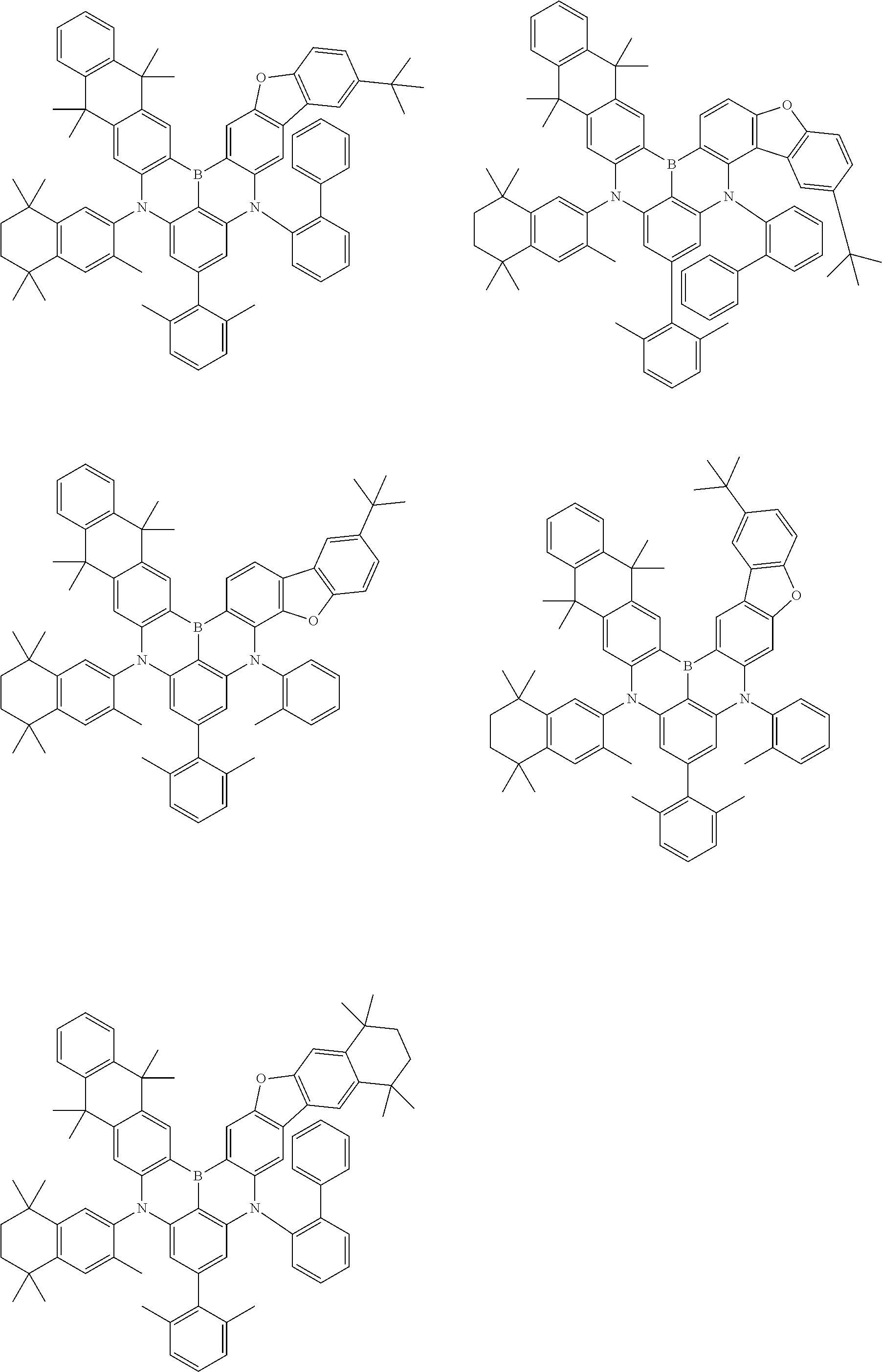

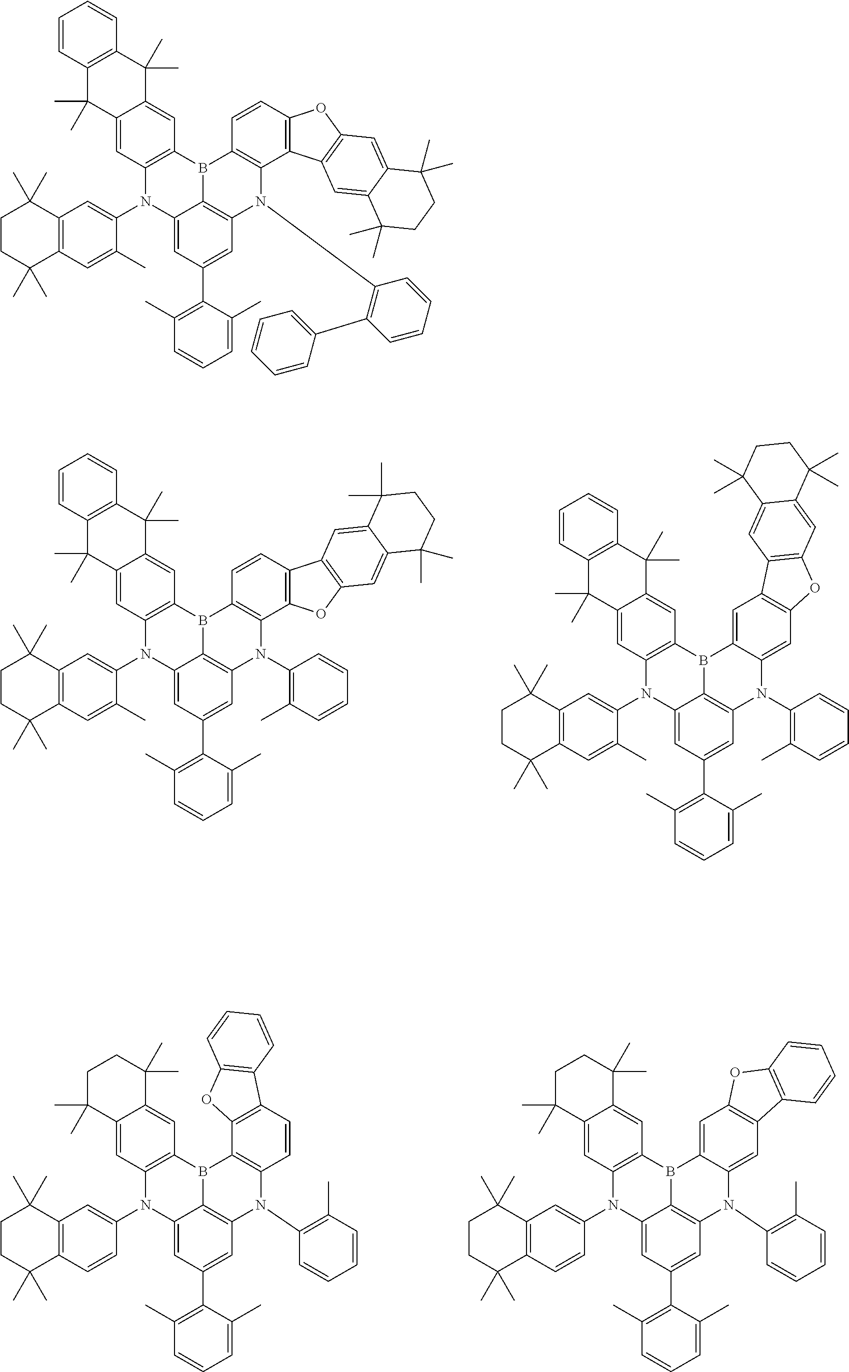

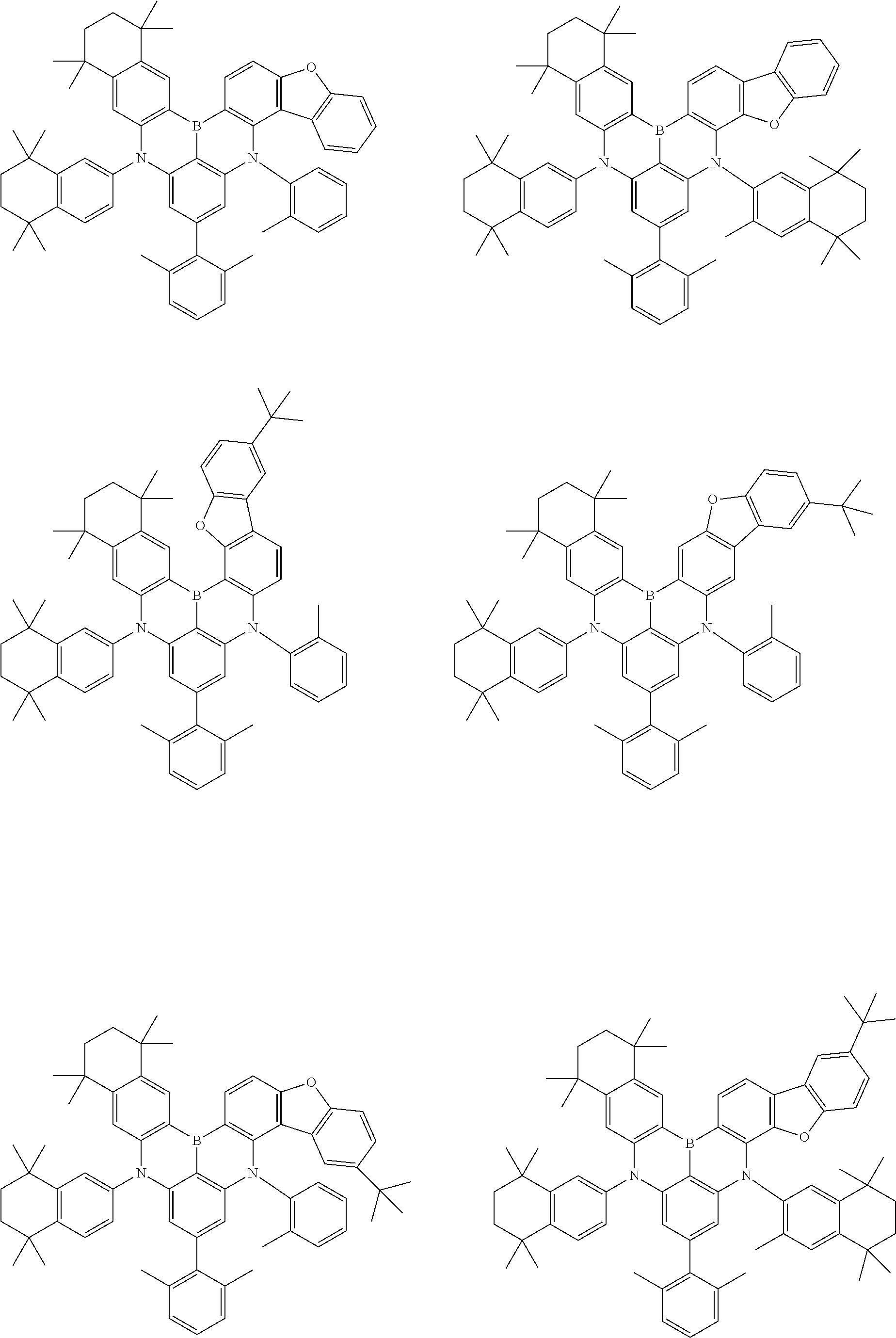

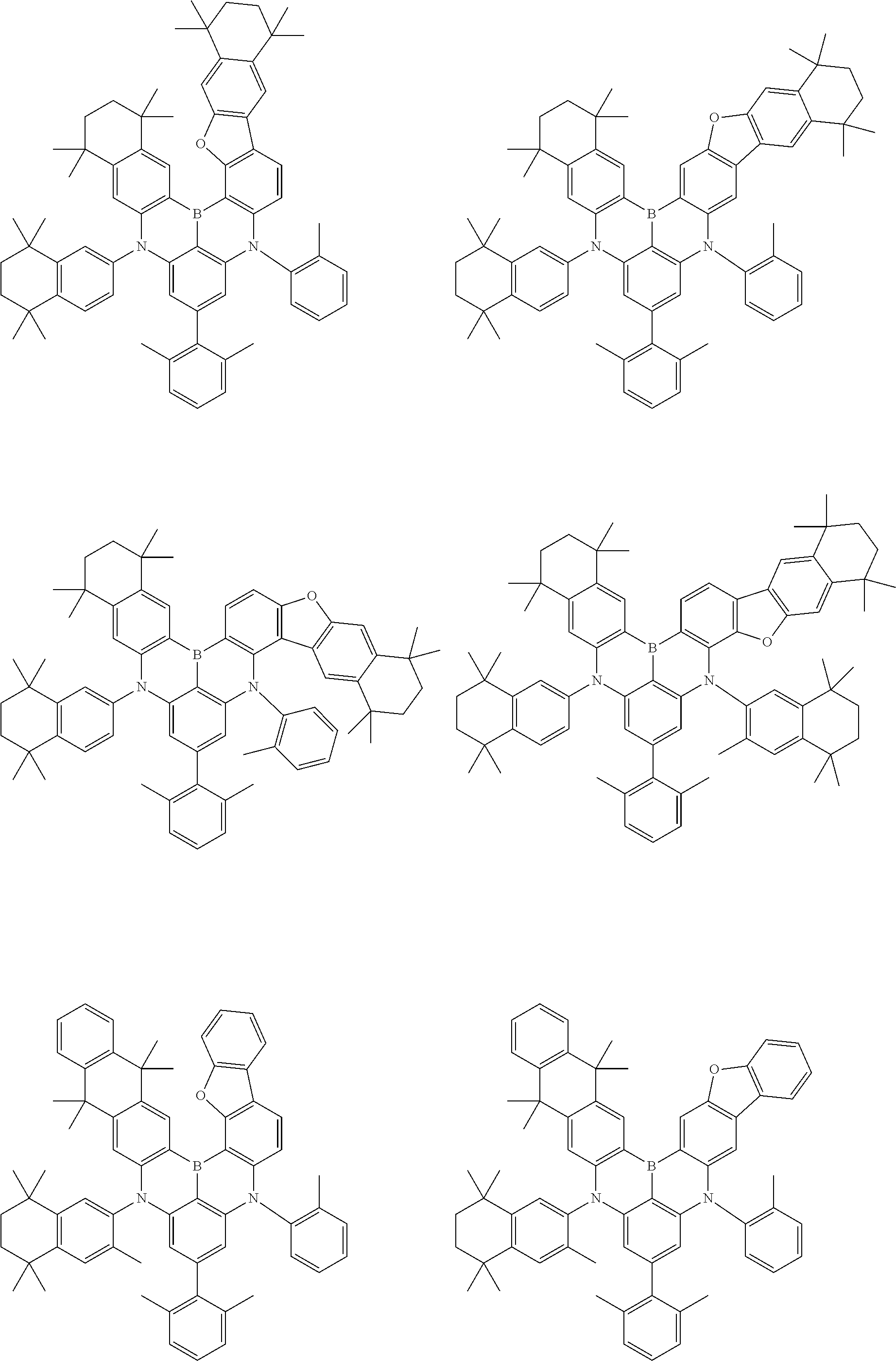

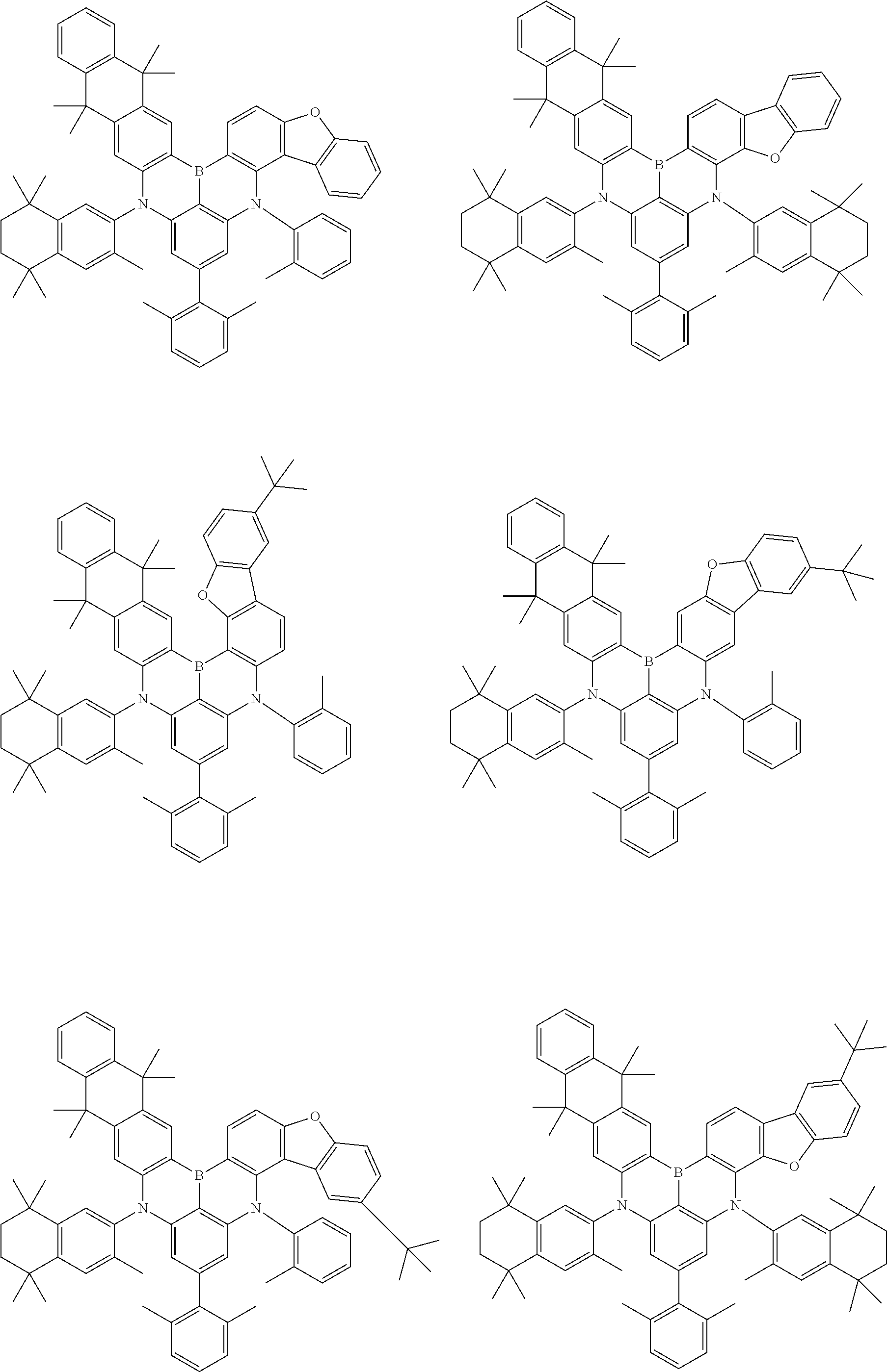

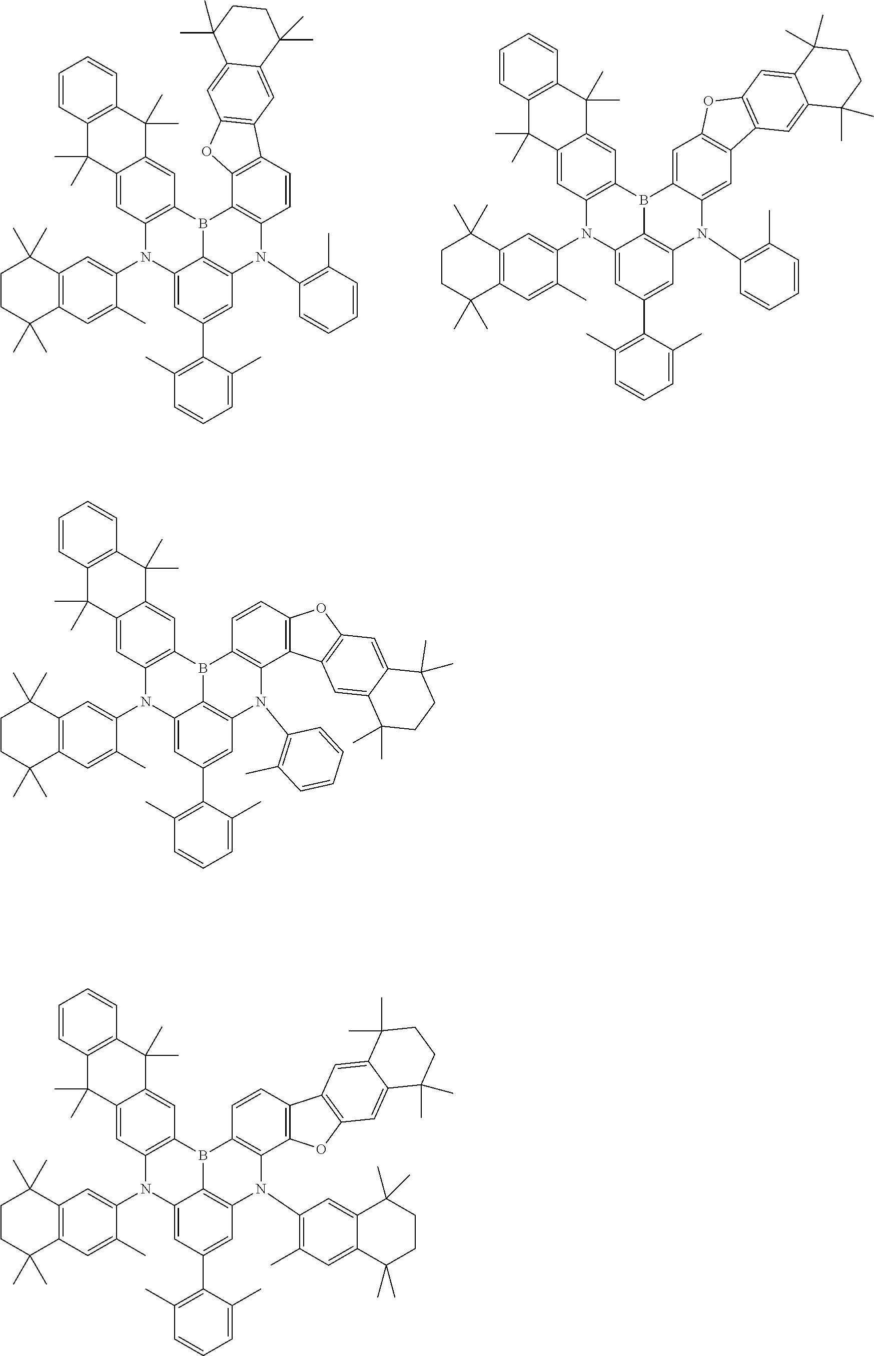

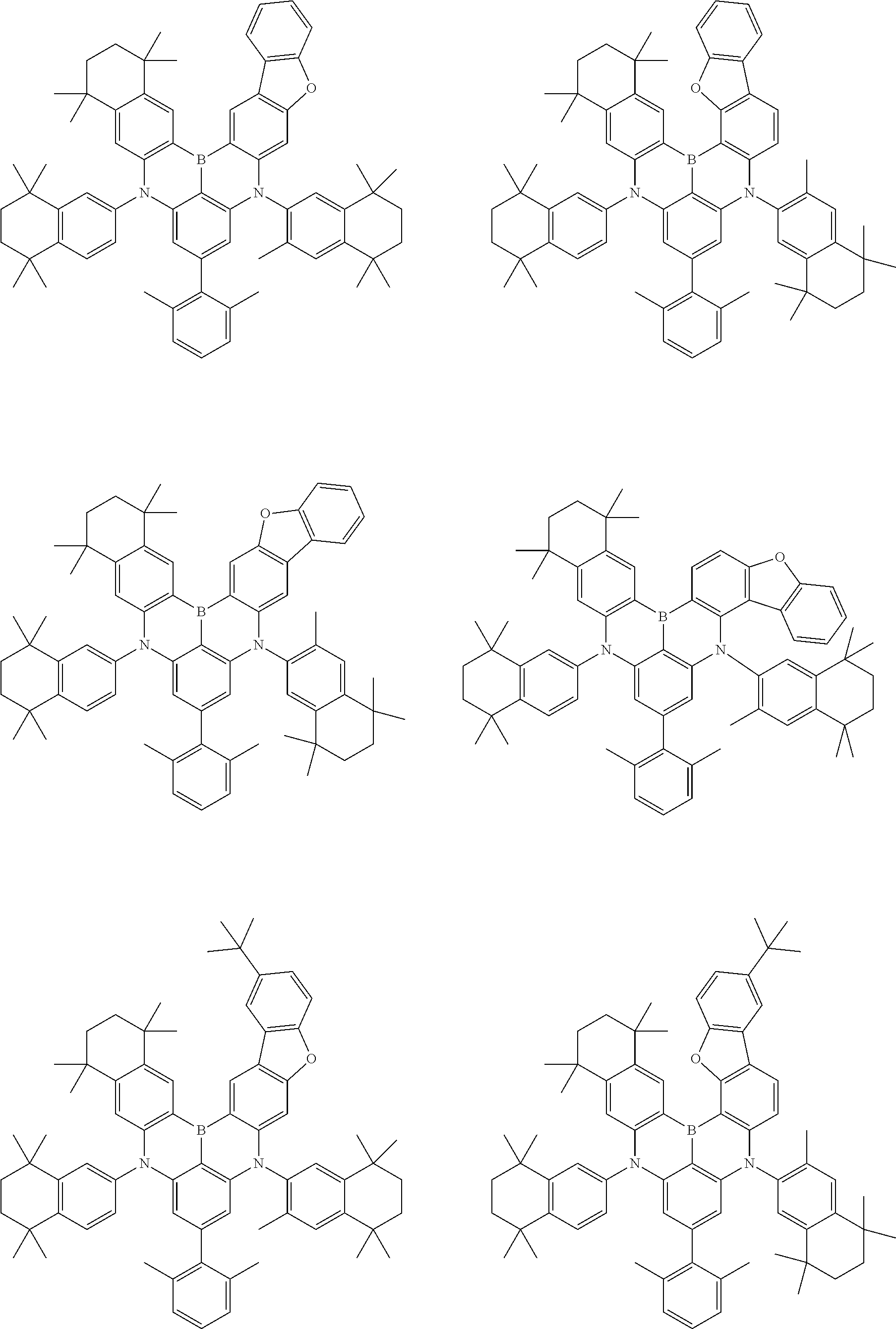

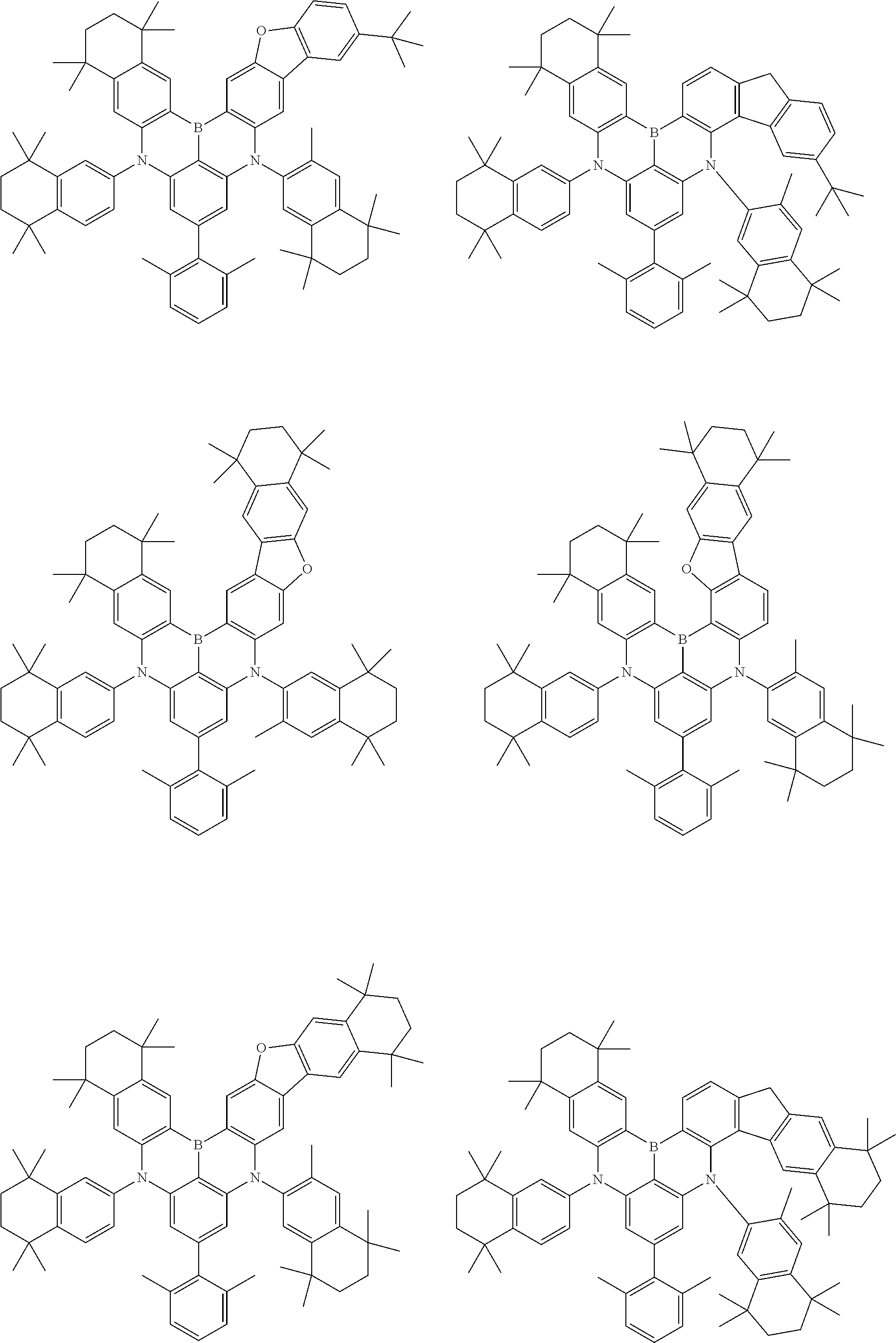

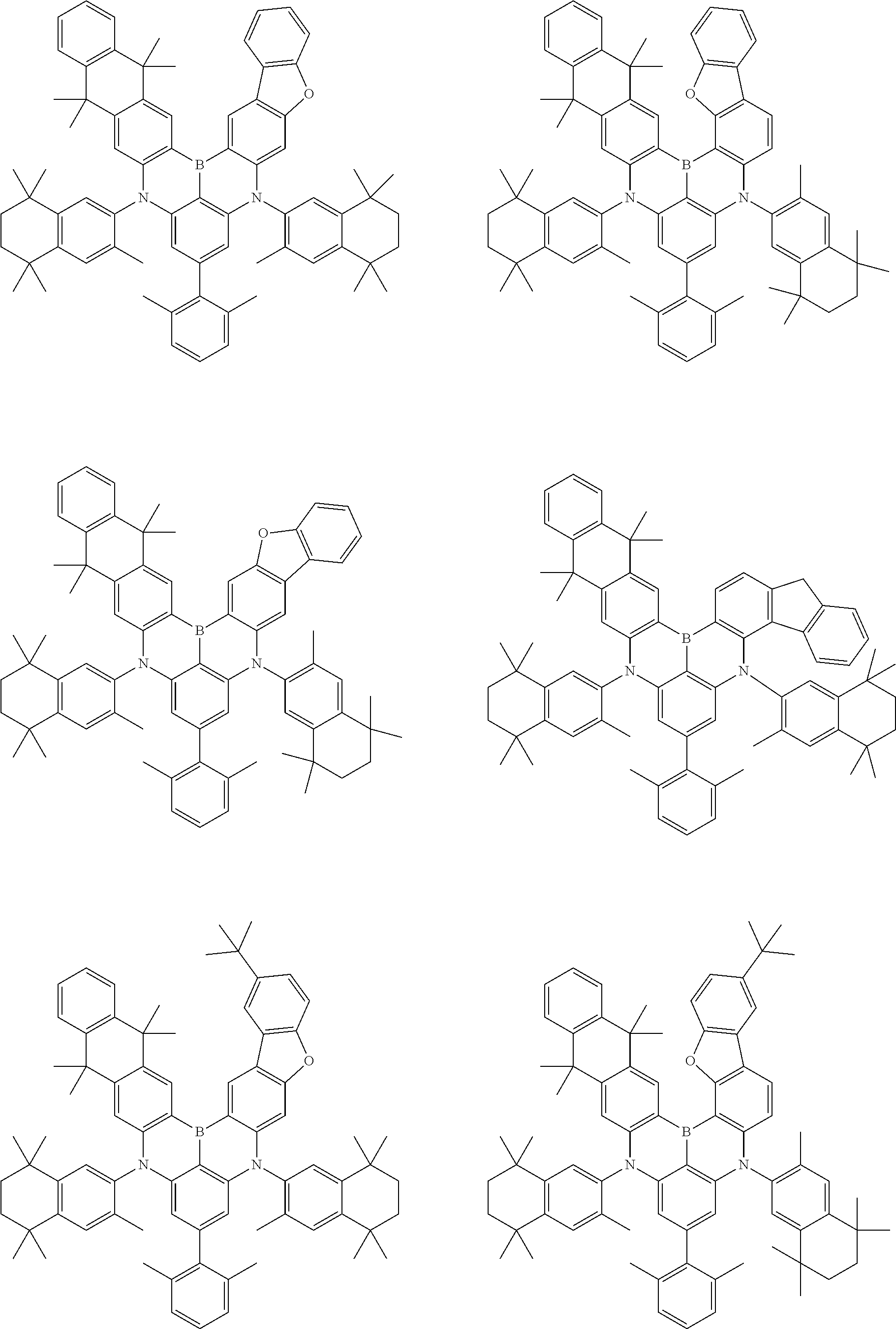

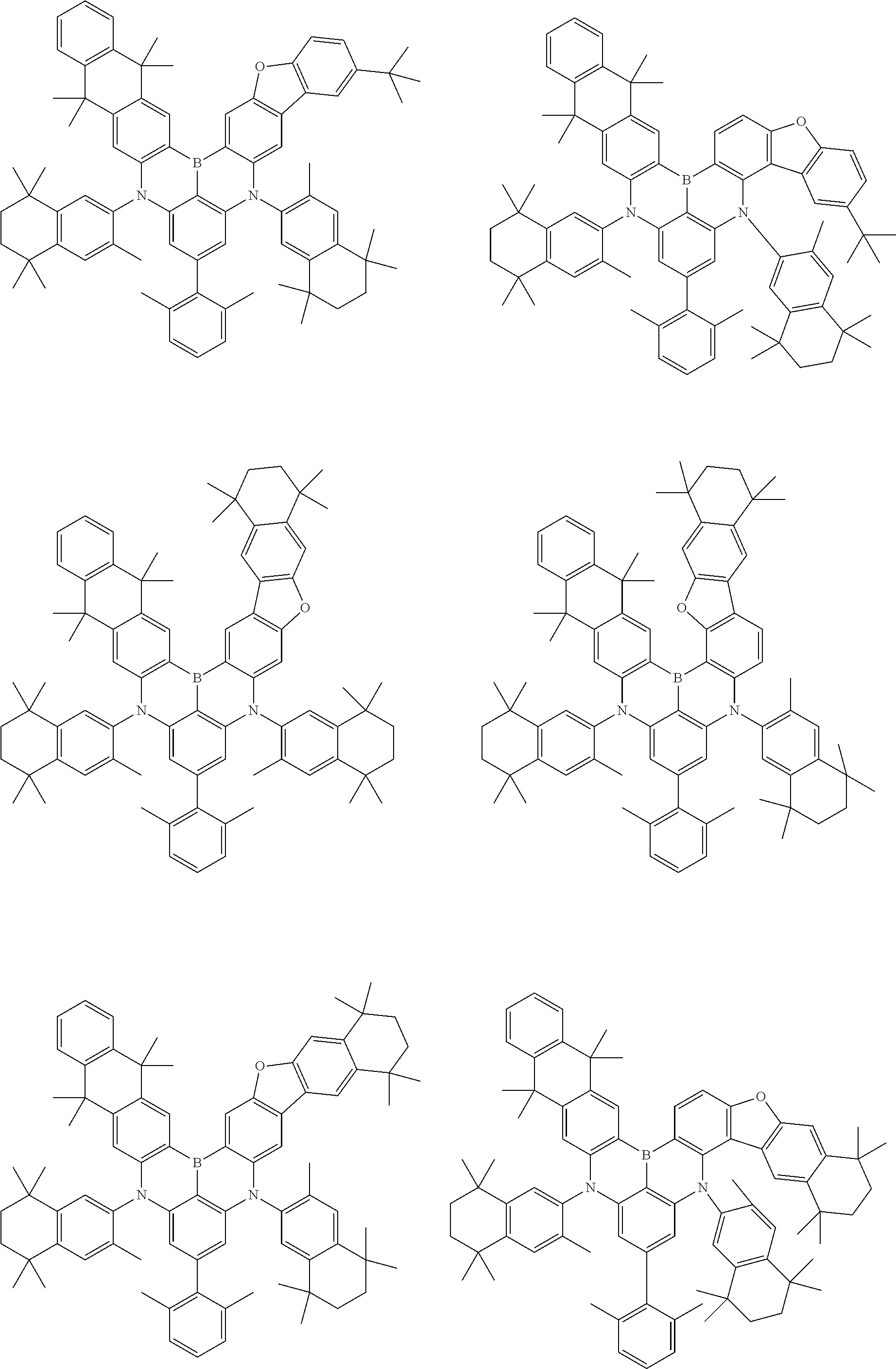

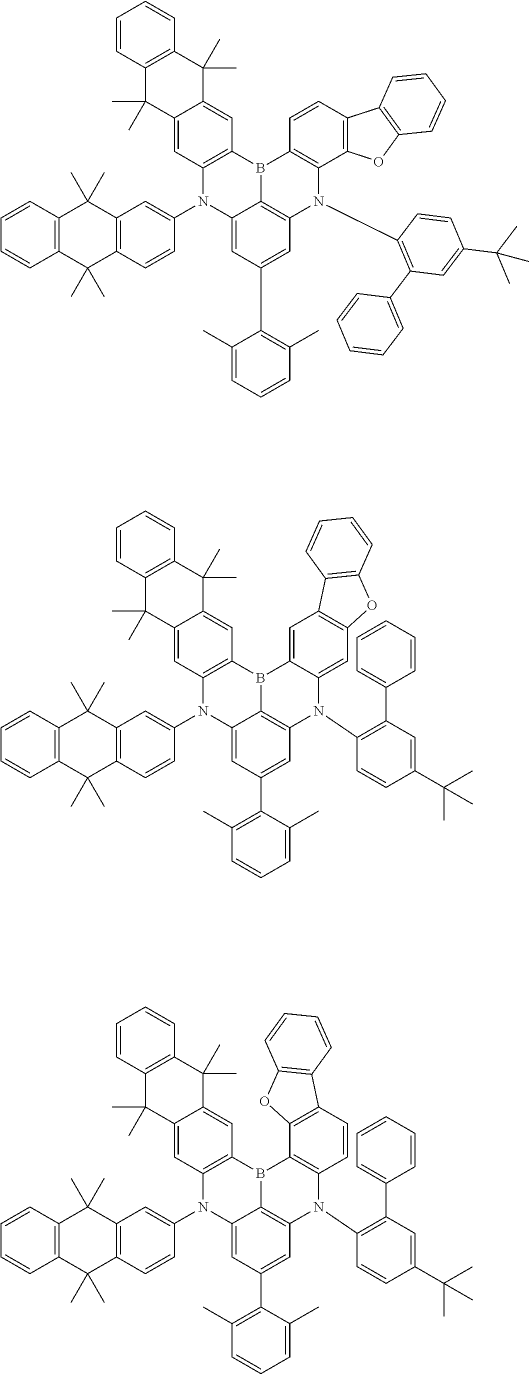 [SMILES: Cc1cccc(C)c1-c1cc2c3c(c1)N(c1ccc(C(C)(C)C)cc1-c1ccccc1)c1c(ccc4c1oc1ccccc14)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)c1ccccc1C2(C)C)C(C)(C)c1ccccc1C3(C)C]

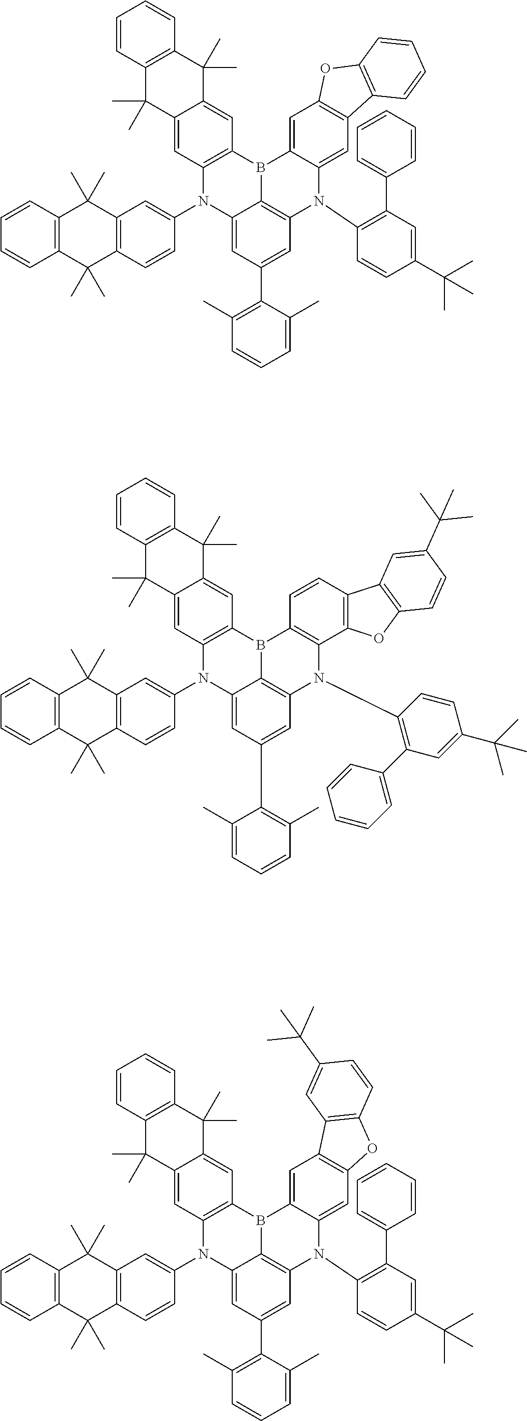 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)oc1ccccc14 ; Cc1cccc(C)c1-c1cc2c3c(c1)N(c1ccc(C(C)(C)C)cc1-c1ccccc1)c1c(ccc4c1oc1ccc(C(C)(C)C)cc14)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1cc4oc5ccc(C(C)(C)C)cc5c4cc1B3c1cc3c(cc1N2c1ccc2c(c1)C(C)(C)c1ccccc1C2(C)C)C(C)(C)c1ccccc1C3(C)C]

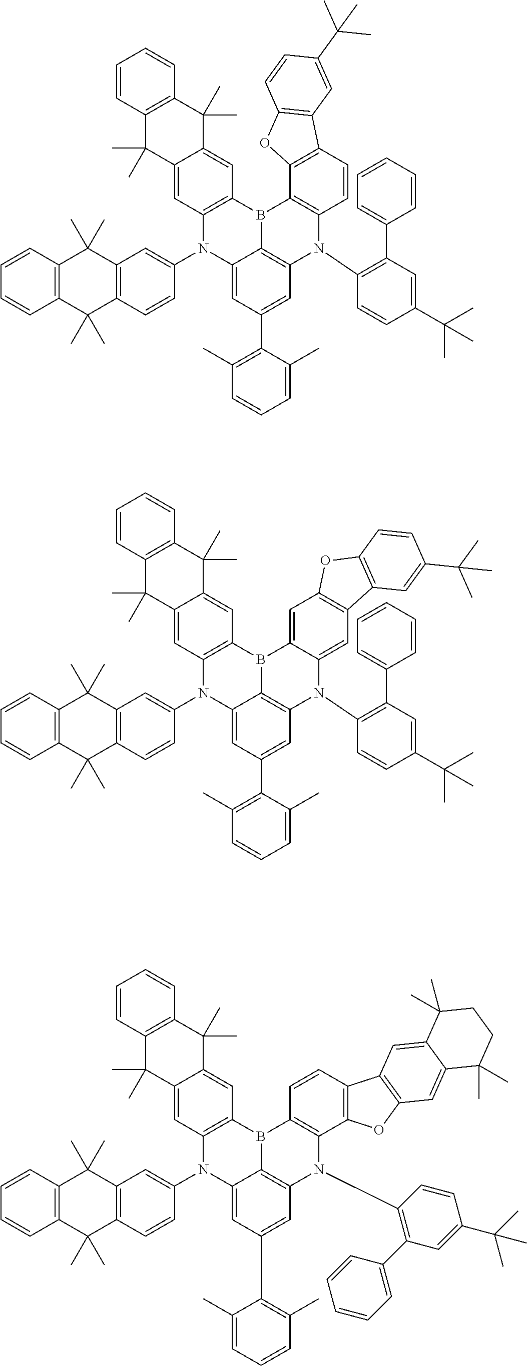 [SMILES: Cc1cccc(C)c1-c1cc2c3c(c1)N(c1ccc(C(C)(C)C)cc1-c1ccccc1)c1ccc4c(oc5ccc(C(C)(C)C)cc54)c1B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)oc1ccc(C(C)(C)C)cc14 ; Cc1cccc(C)c1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C]

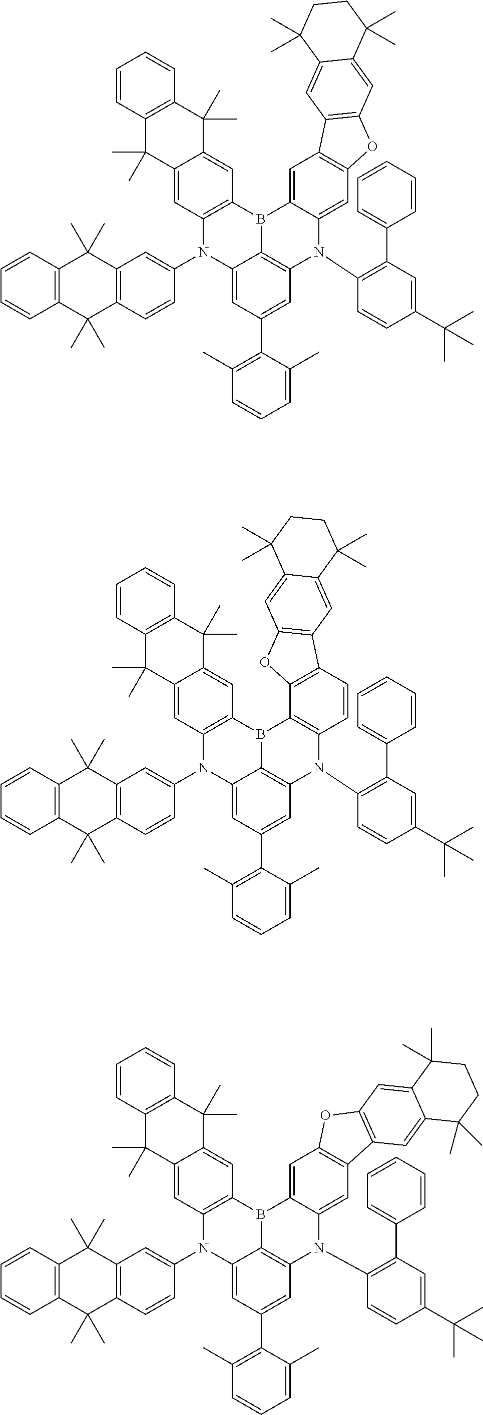 [SMILES: Cc1cccc(C)c1-c1cc2c3c(c1)N(c1ccc(C(C)(C)C)cc1-c1ccccc1)c1cc4oc5cc6c(cc5c4cc1B3c1cc3c(cc1N2c1ccc2c(c1)C(C)(C)c1ccccc1C2(C)C)C(C)(C)c1ccccc1C3(C)C)C(C)(C)CCC6(C)C ; Cc1cccc(C)c1-c1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)oc1cc2c(cc14)C(C)(C)CCC2(C)C]

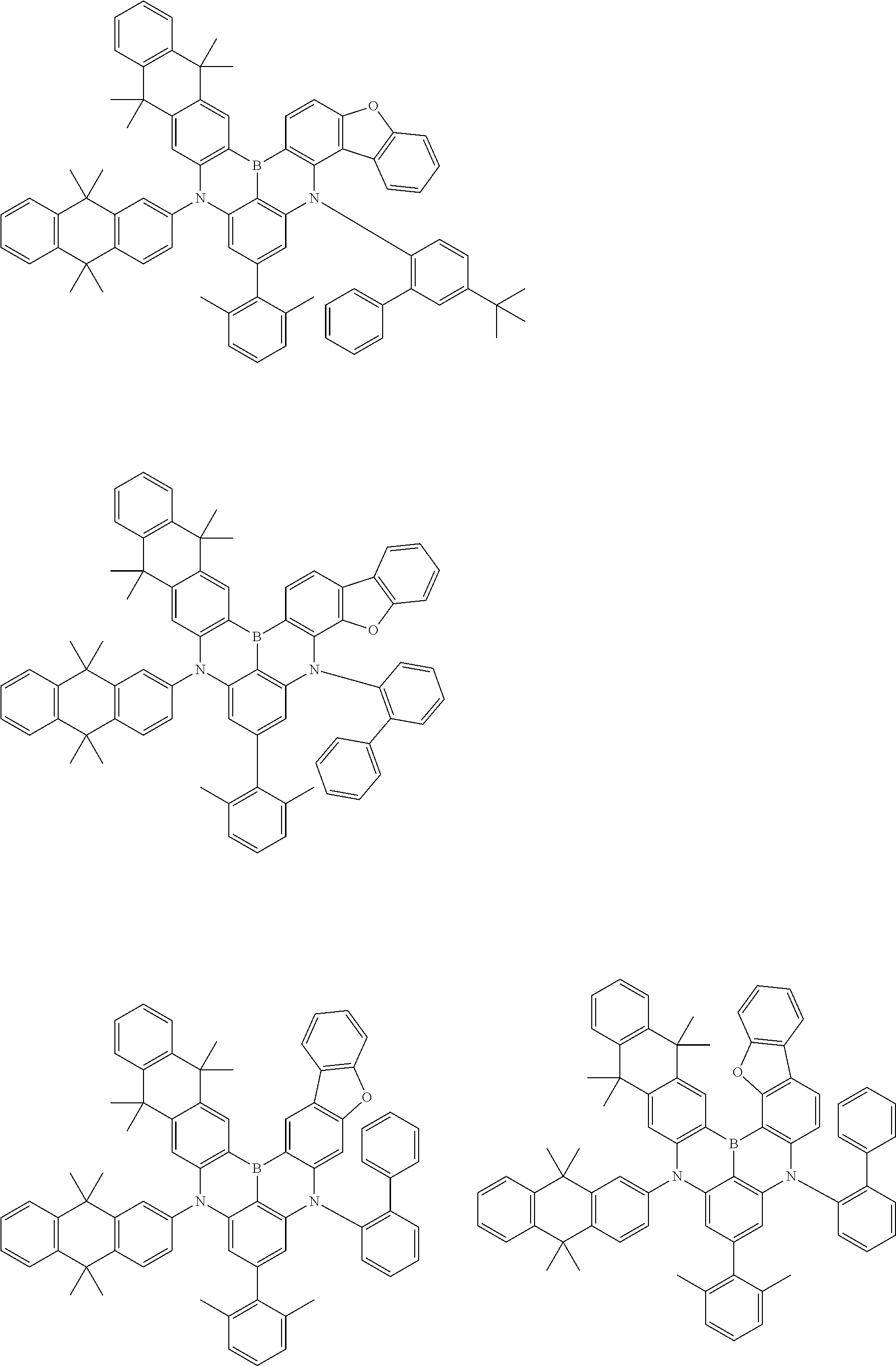

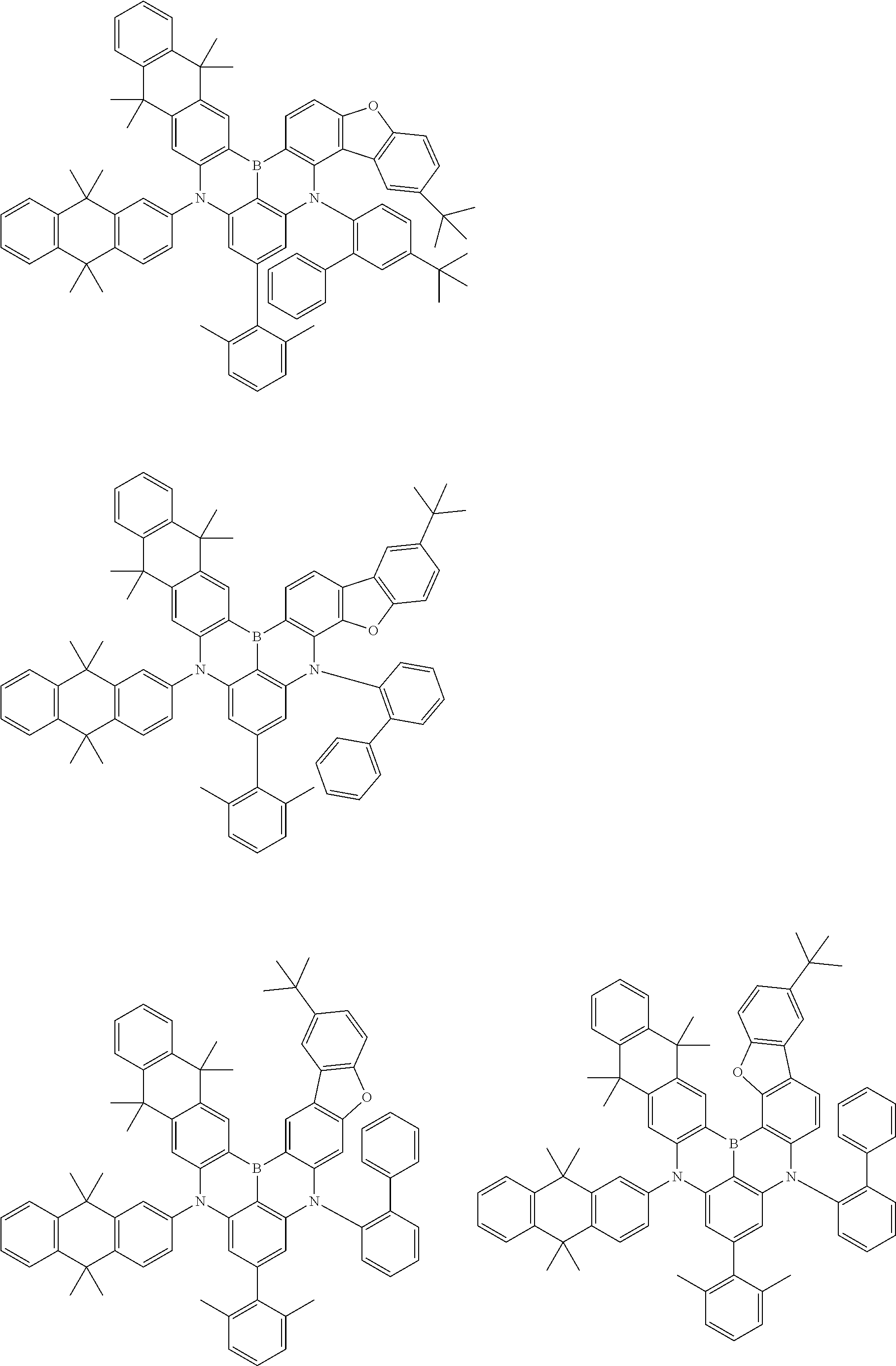

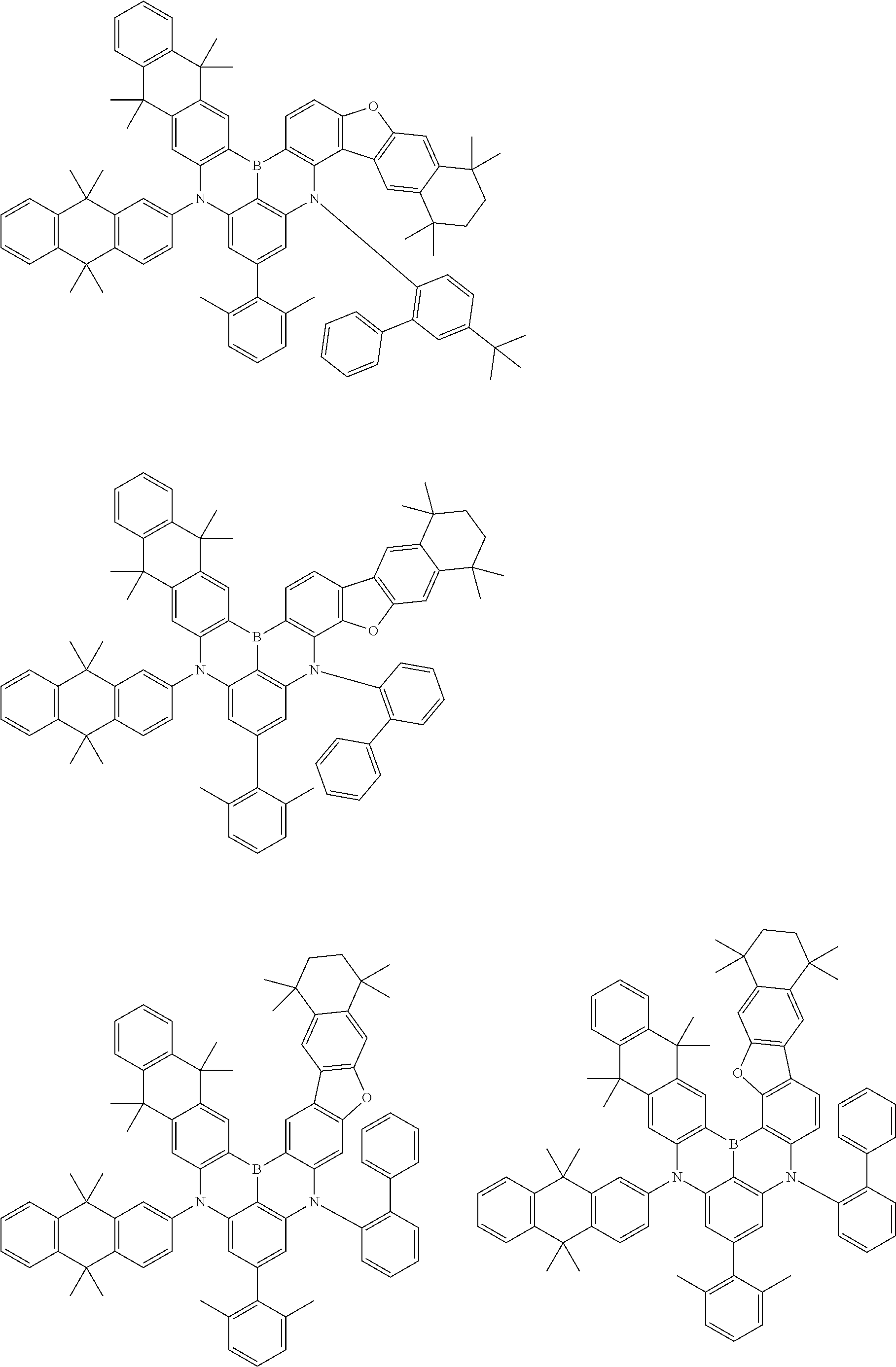

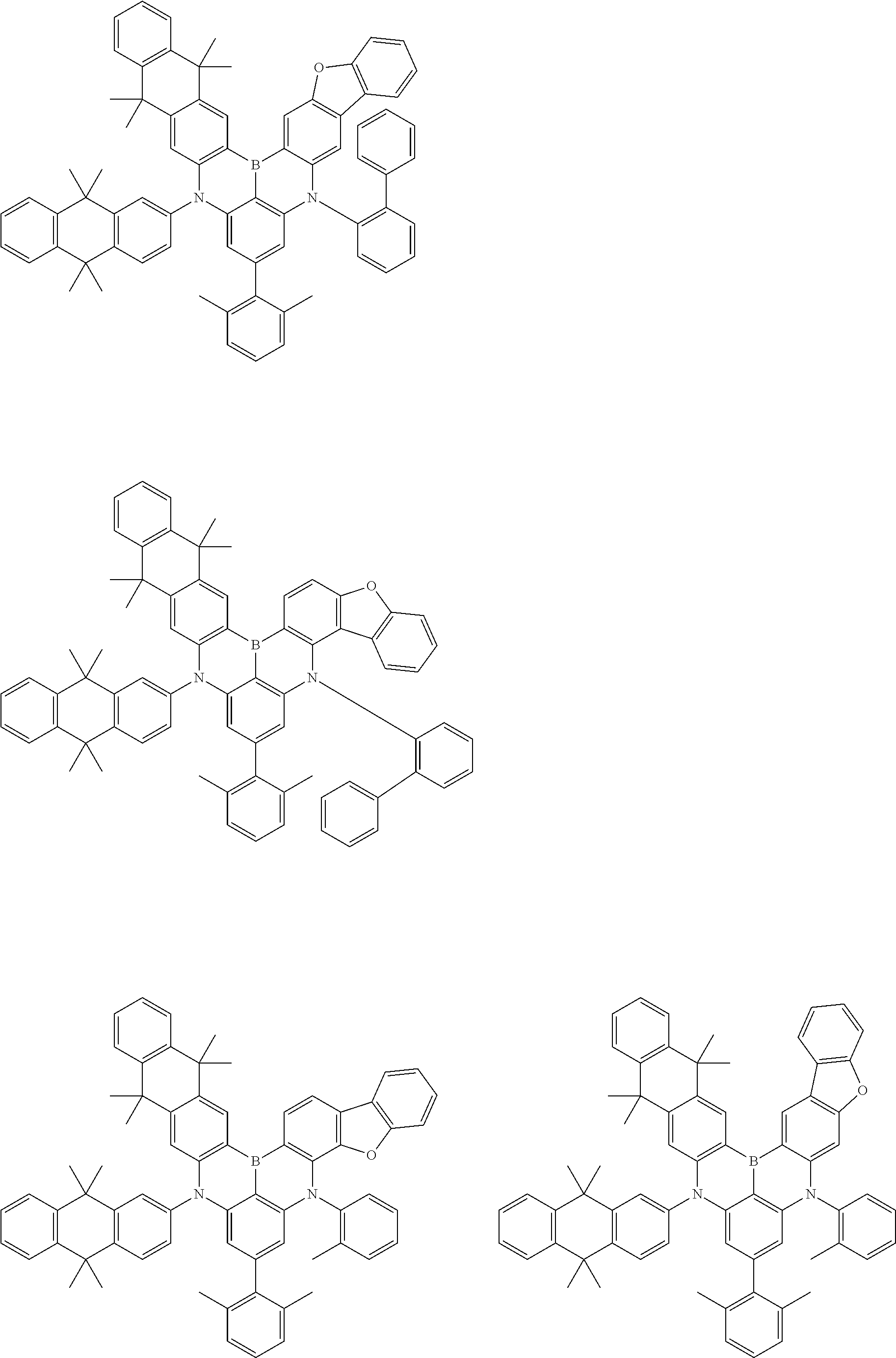

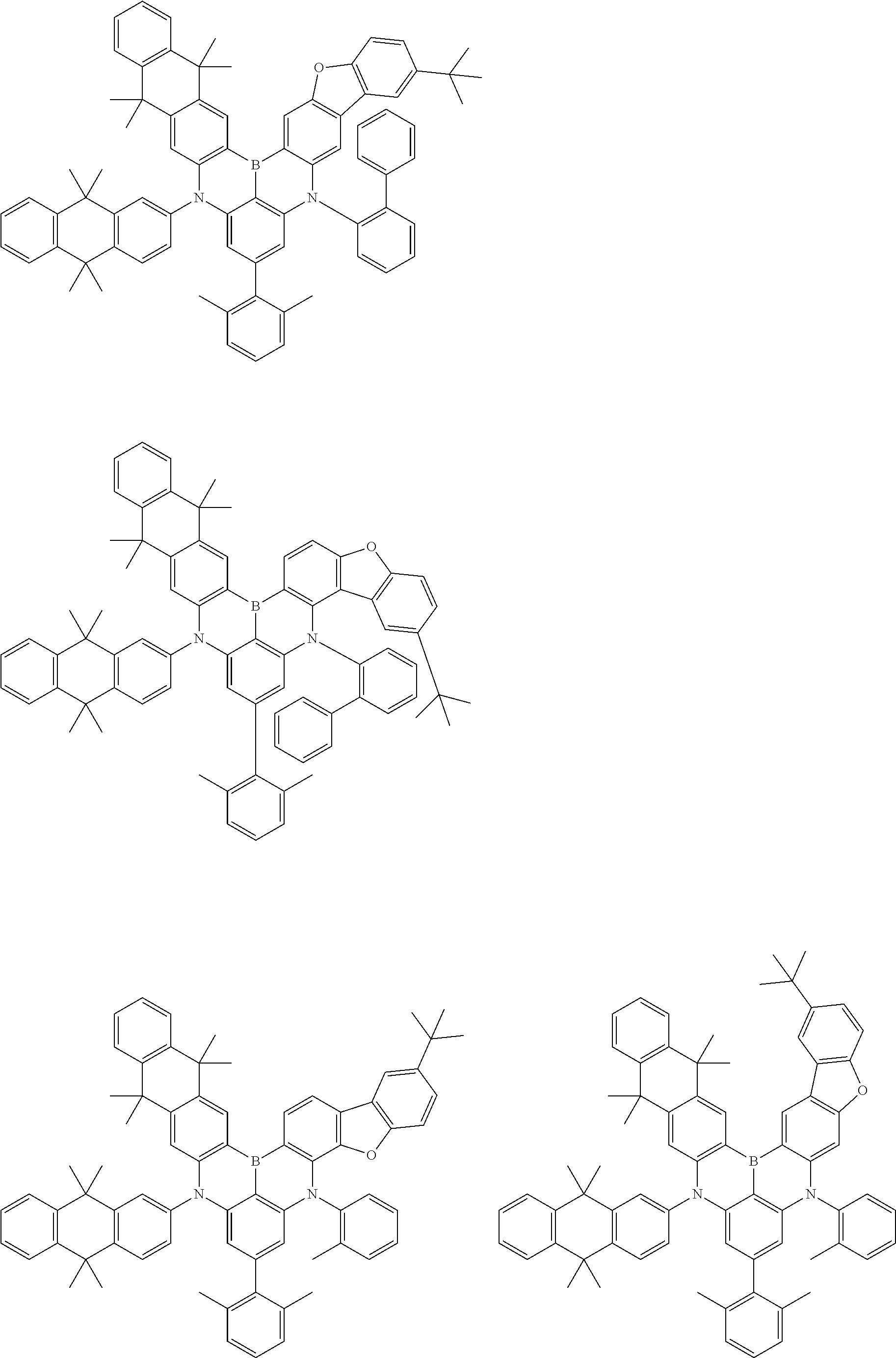

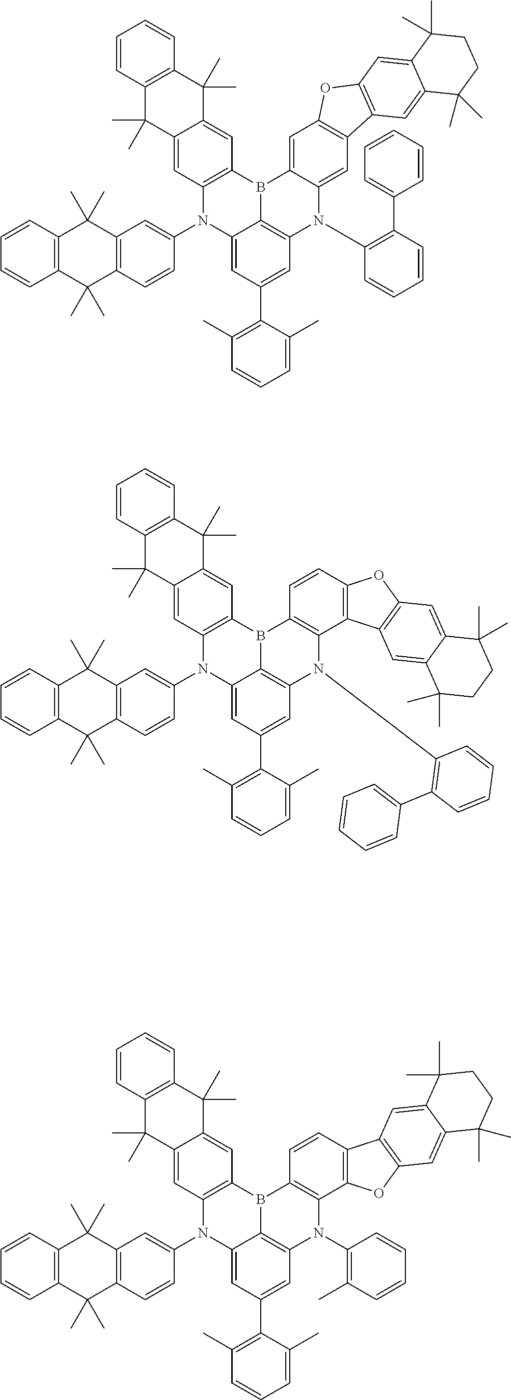 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)oc1cc2c(cc14)C(C)(C)CCC2(C)C ; Cc1cccc(C)c1-c1cc2c3c(c1)N(c1ccccc1-c1ccccc1)c1c(ccc4oc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(oc4cc5c(cc43)C(C)(C)CCC5(C)C)c21]

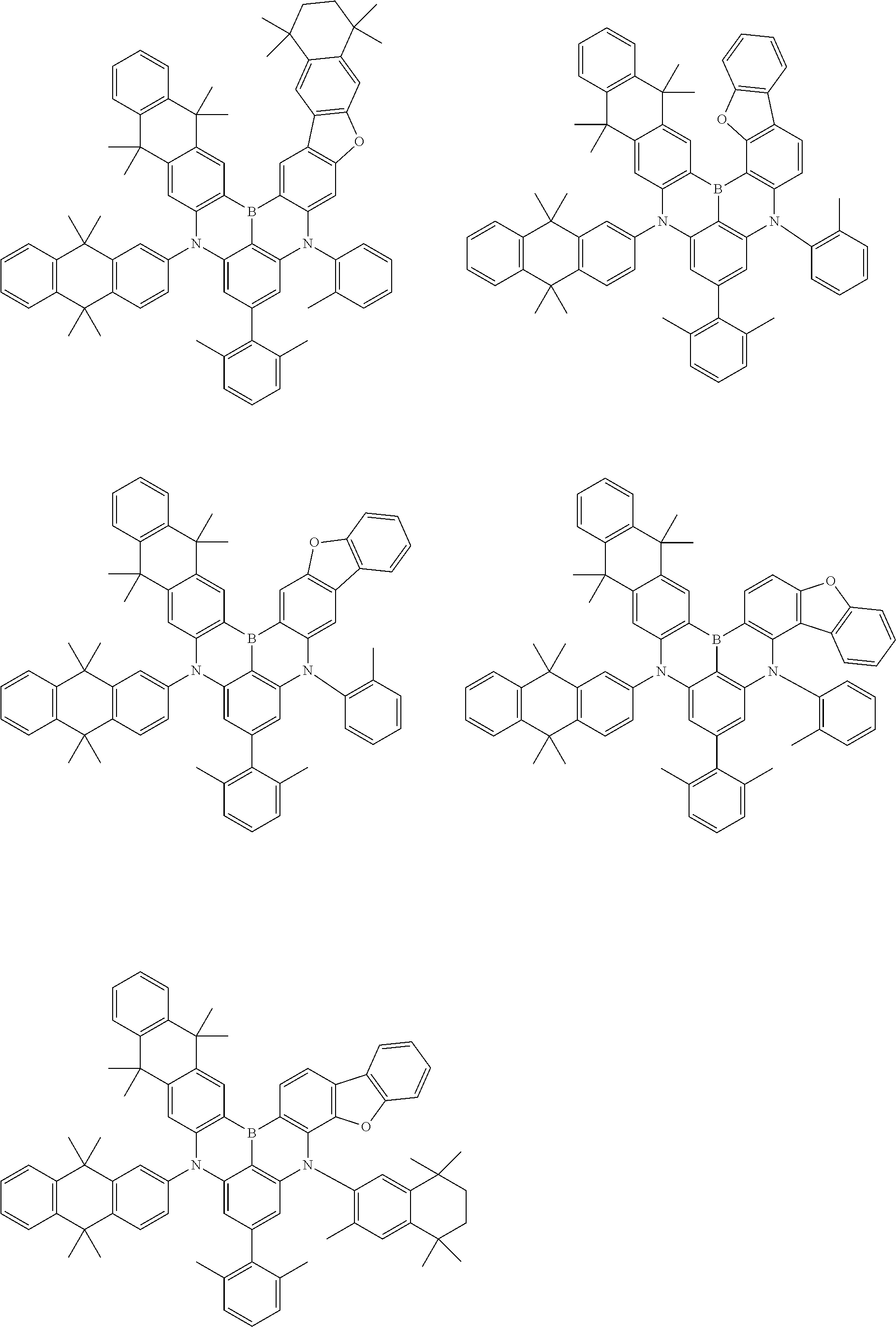

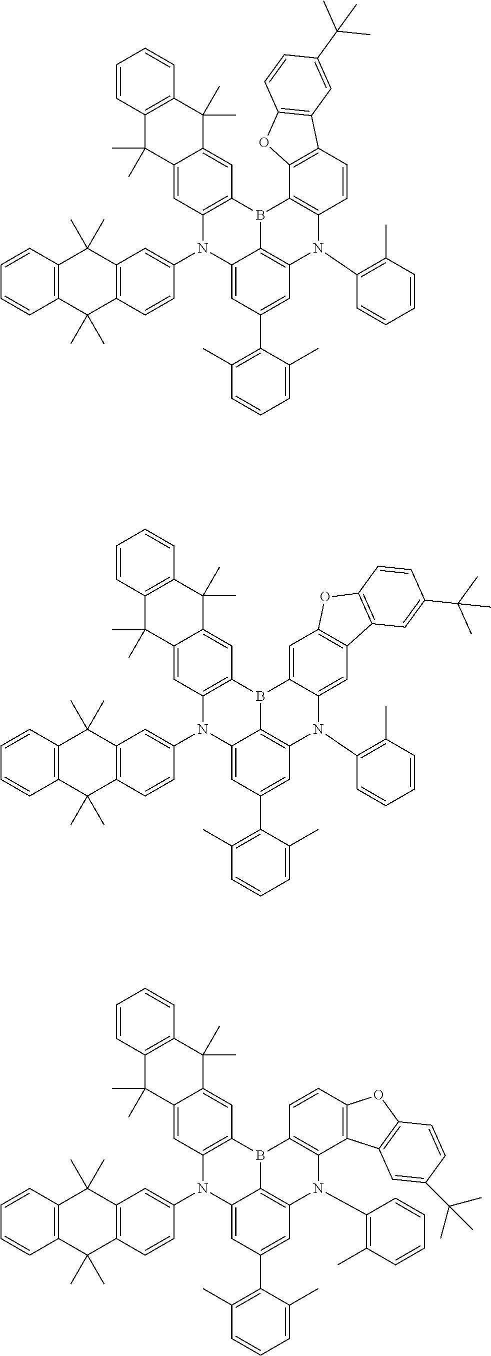 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2oc2ccc(C(C)(C)C)cc21 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)oc1ccc(C(C)(C)C)cc13 ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3oc4ccc(C(C)(C)C)cc4c3c21]

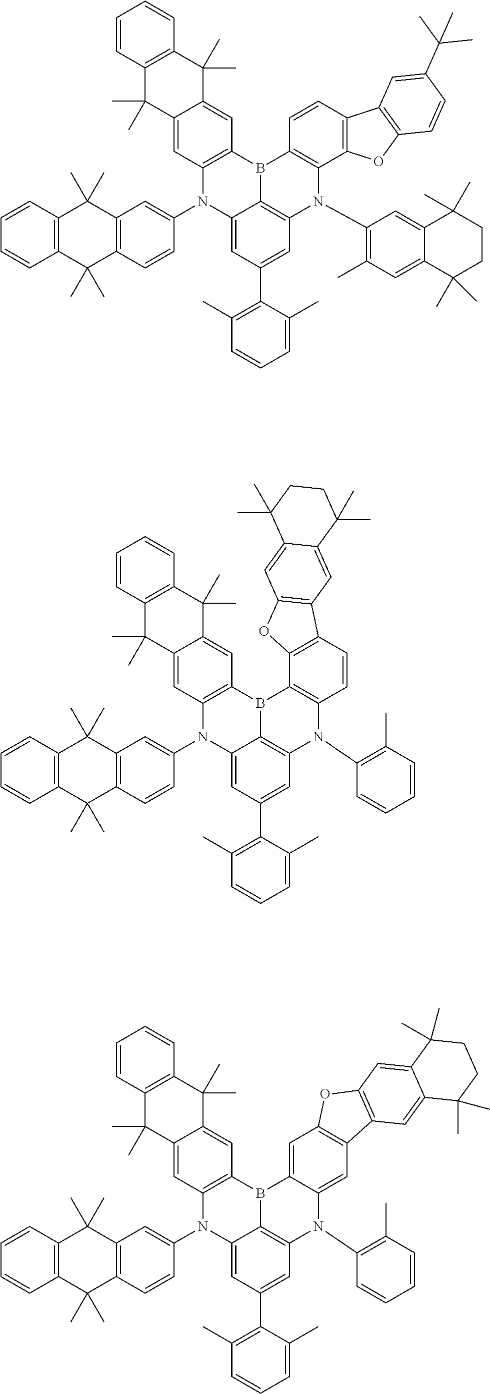 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(oc5ccc(C(C)(C)C)cc54)c31)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2oc2cc3c(cc21)C(C)(C)CCC3(C)C ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)oc1cc2c(cc13)C(C)(C)CCC2(C)C]

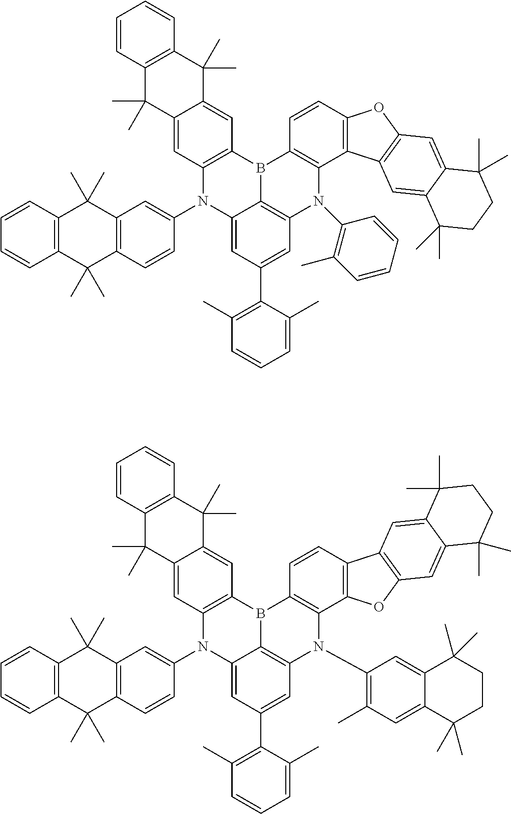 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3oc4cc5c(cc4c3c21)C(C)(C)CCC5(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(oc5cc6c(cc54)C(C)(C)CCC6(C)C)c31)C(C)(C)CCC2(C)C]

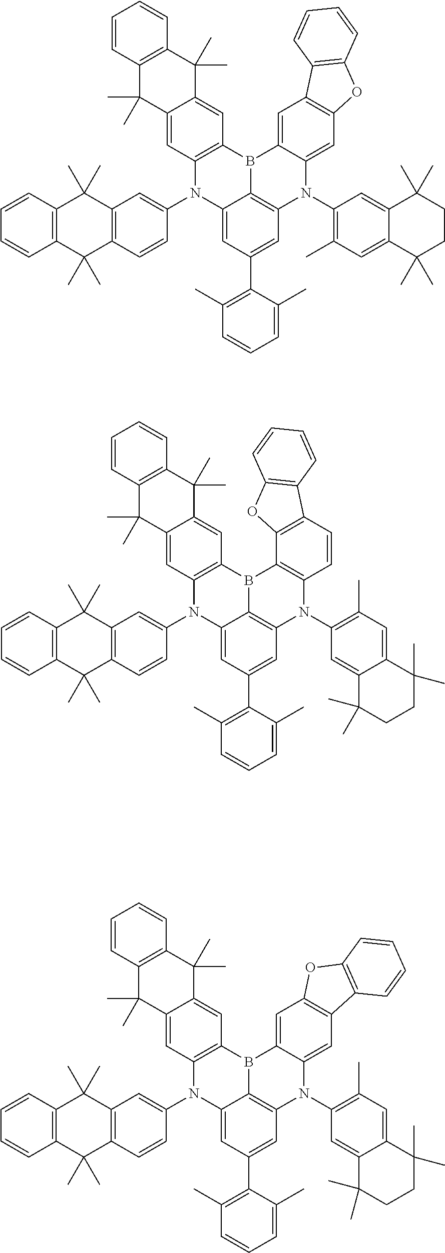 [SMILES: Cc1cc2c(cc1N1c3cc4oc5ccccc5c4cc3B3c4cc5c(cc4N(c4ccc6c(c4)C(C)(C)c4ccccc4C6(C)C)c4cc(-c6c(C)cccc6C)cc1c43)C(C)(C)c1ccccc1C5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3oc3ccccc31)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)oc1ccccc14)C(C)(C)CCC2(C)C]

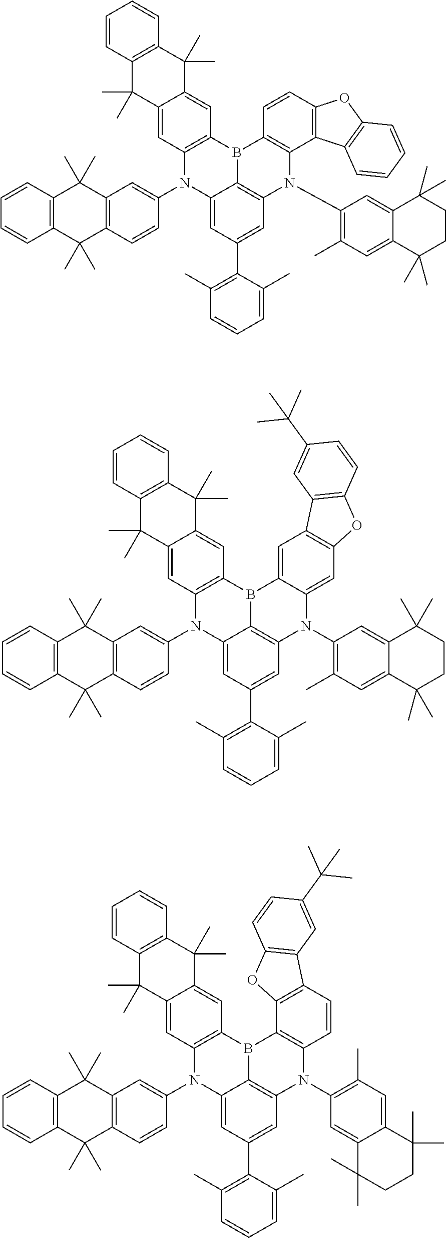 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4oc5ccccc5c4c31)C(C)(C)CCC2(C)C ; Cc1cc2c(cc1N1c3cc4oc5ccc(C(C)(C)C)cc5c4cc3B3c4cc5c(cc4N(c4ccc6c(c4)C(C)(C)c4ccccc4C6(C)C)c4cc(-c6c(C)cccc6C)cc1c43)C(C)(C)c1ccccc1C5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3oc3ccc(C(C)(C)C)cc31)C(C)(C)CCC2(C)C]

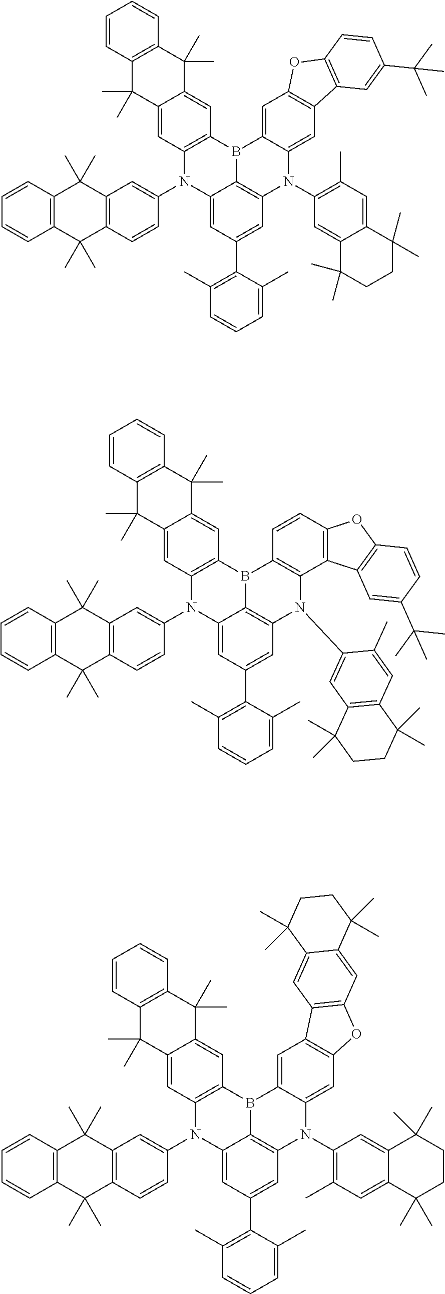 [SMILES: Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)oc1ccc(C(C)(C)C)cc14)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4oc5ccc(C(C)(C)C)cc5c4c31)C(C)(C)CCC2(C)C ; Cc1cc2c(cc1N1c3cc4oc5cc6c(cc5c4cc3B3c4cc5c(cc4N(c4ccc7c(c4)C(C)(C)c4ccccc4C7(C)C)c4cc(-c7c(C)cccc7C)cc1c43)C(C)(C)c1ccccc1C5(C)C)C(C)(C)CCC6(C)C)C(C)(C)CCC2(C)C]

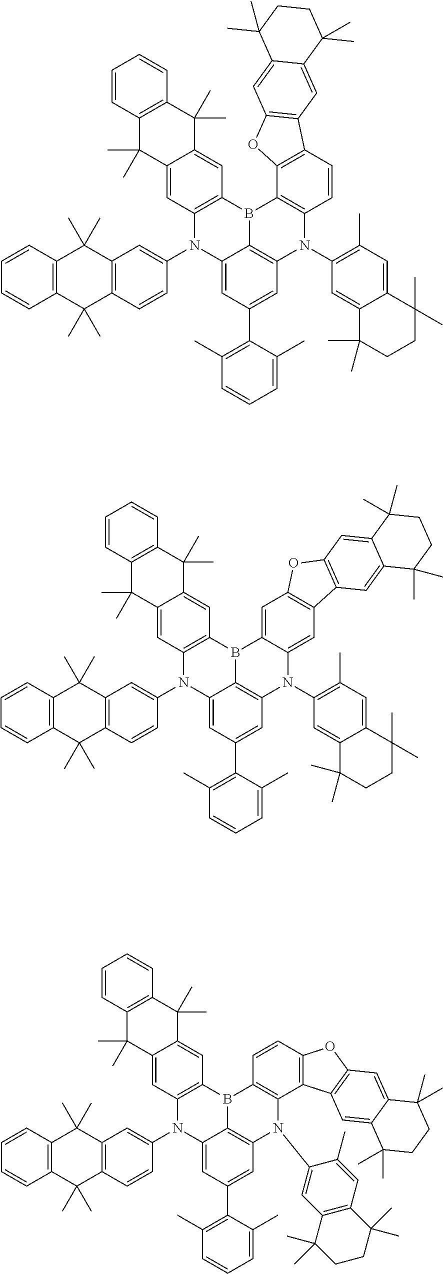 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3oc3cc4c(cc31)C(C)(C)CCC4(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)oc1cc3c(cc14)C(C)(C)CCC3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4oc5cc6c(cc5c4c31)C(C)(C)CCC6(C)C)C(C)(C)CCC2(C)C]

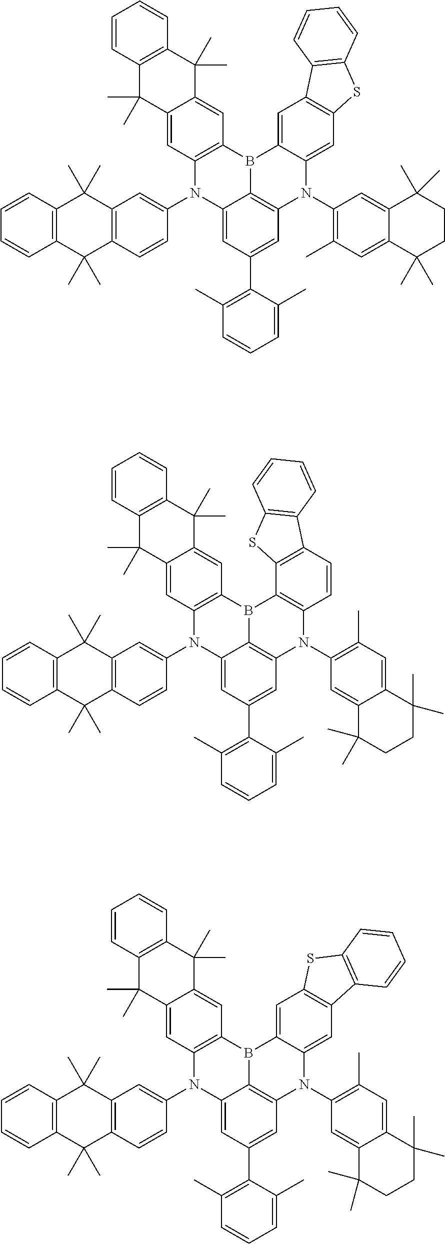 [SMILES: Cc1cc2c(cc1N1c3cc4sc5ccccc5c4cc3B3c4cc5c(cc4N(c4ccc6c(c4)C(C)(C)c4ccccc4C6(C)C)c4cc(-c6c(C)cccc6C)cc1c43)C(C)(C)c1ccccc1C5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3sc3ccccc31)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)sc1ccccc14)C(C)(C)CCC2(C)C]

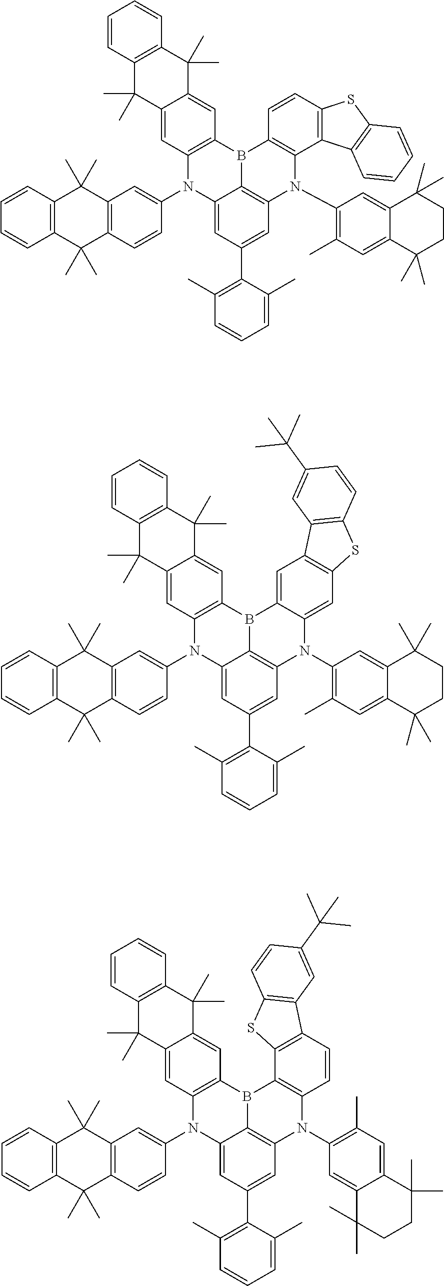 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4sc5ccccc5c4c31)C(C)(C)CCC2(C)C ; Cc1cc2c(cc1N1c3cc4sc5ccc(C(C)(C)C)cc5c4cc3B3c4cc5c(cc4N(c4ccc6c(c4)C(C)(C)c4ccccc4C6(C)C)c4cc(-c6c(C)cccc6C)cc1c43)C(C)(C)c1ccccc1C5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3sc3ccc(C(C)(C)C)cc31)C(C)(C)CCC2(C)C]

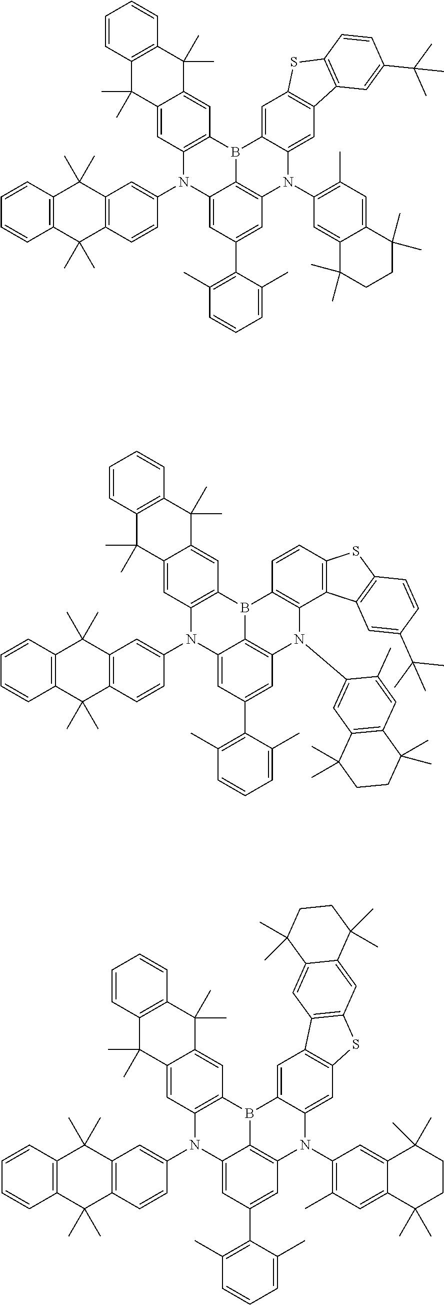 [SMILES: Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)sc1ccc(C(C)(C)C)cc14)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4sc5ccc(C(C)(C)C)cc5c4c31)C(C)(C)CCC2(C)C ; Cc1cc2c(cc1N1c3cc4sc5cc6c(cc5c4cc3B3c4cc5c(cc4N(c4ccc7c(c4)C(C)(C)c4ccccc4C7(C)C)c4cc(-c7c(C)cccc7C)cc1c43)C(C)(C)c1ccccc1C5(C)C)C(C)(C)CCC6(C)C)C(C)(C)CCC2(C)C]

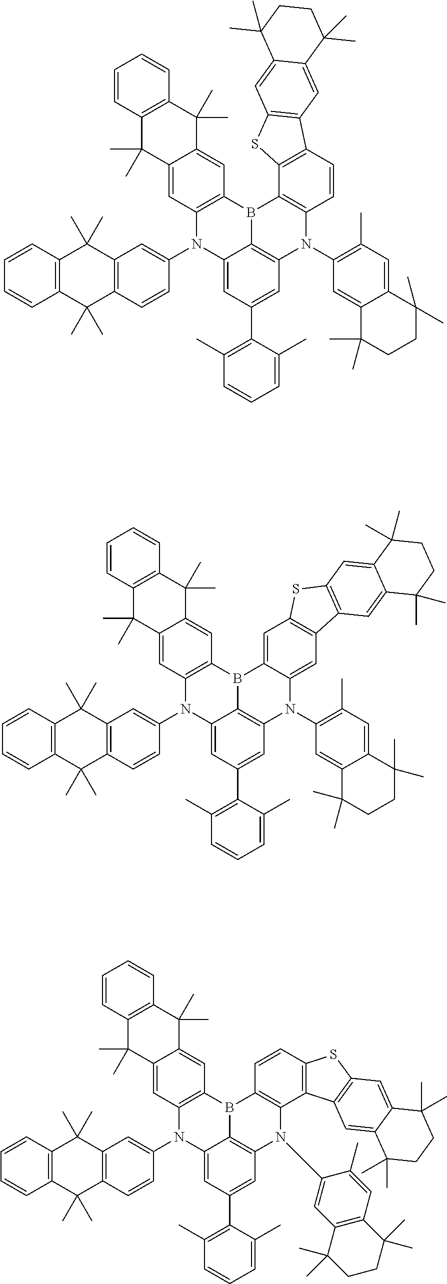 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3sc3cc4c(cc31)C(C)(C)CCC4(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)sc1cc3c(cc14)C(C)(C)CCC3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4sc5cc6c(cc5c4c31)C(C)(C)CCC6(C)C)C(C)(C)CCC2(C)C]

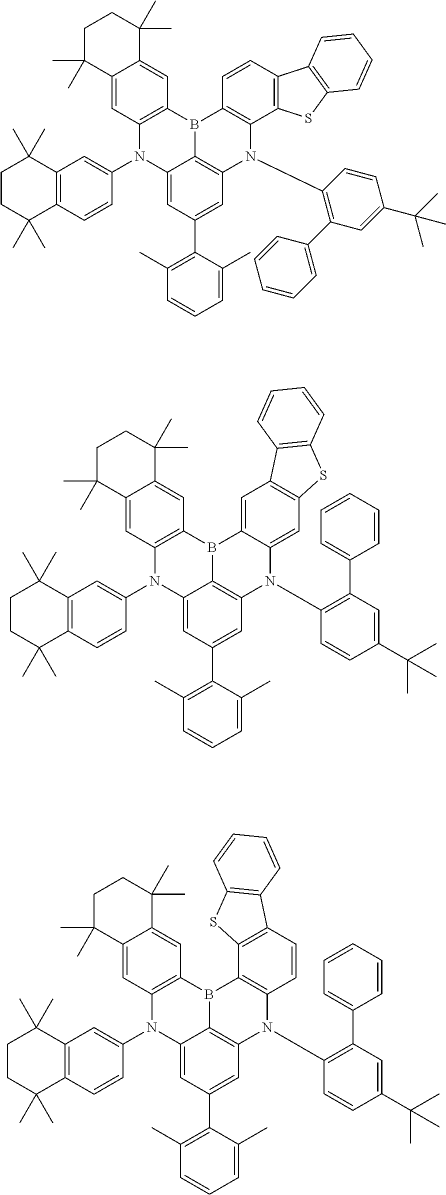 [SMILES: Cc1cccc(C)c1-c1cc2c3c(c1)N(c1ccc(C(C)(C)C)cc1-c1ccccc1)c1c(ccc4c1sc1ccccc14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4sc5ccccc5c4cc1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1ccc4c(sc5ccccc54)c1B3c1cc3c(cc1N2c1ccc2c(c1)C(C)(C)CCC2(C)C)C(C)(C)CCC3(C)C]

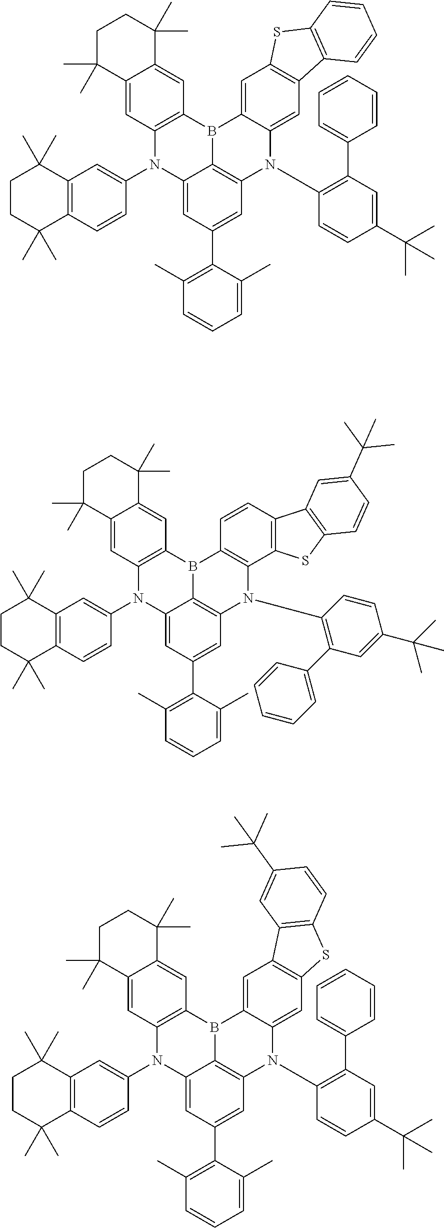 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1ccccc14 ; Cc1cccc(C)c1-c1cc2c3c(c1)N(c1ccc(C(C)(C)C)cc1-c1ccccc1)c1c(ccc4c1sc1ccc(C(C)(C)C)cc14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4sc5ccc(C(C)(C)C)cc5c4cc1B3c1cc3c(cc1N2c1ccc2c(c1)C(C)(C)CCC2(C)C)C(C)(C)CCC3(C)C]

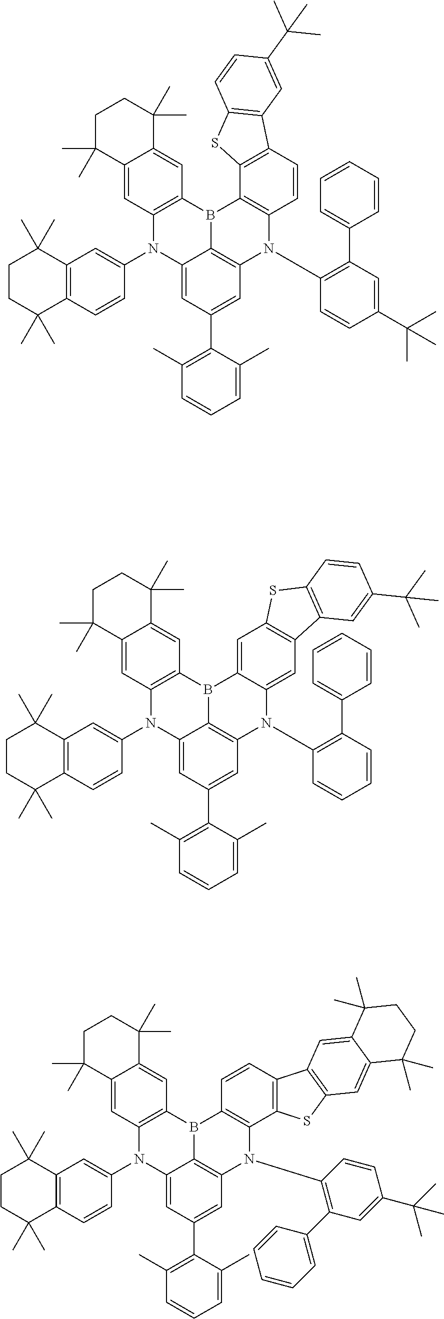 [SMILES: Cc1cccc(C)c1-c1cc2c3c(c1)N(c1ccc(C(C)(C)C)cc1-c1ccccc1)c1ccc4c(sc5ccc(C(C)(C)C)cc54)c1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1ccc(C(C)(C)C)cc14 ; Cc1cccc(C)c1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C]

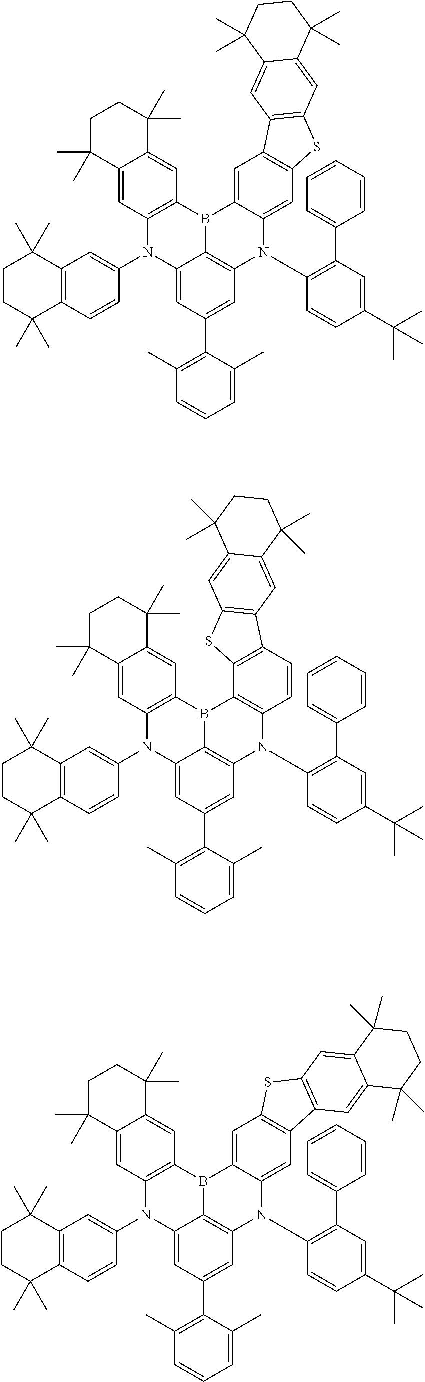 [SMILES: Cc1cccc(C)c1-c1cc2c3c(c1)N(c1ccc(C(C)(C)C)cc1-c1ccccc1)c1cc4sc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1cccc(C)c1-c1cc2c3c(c1)N(c1ccc(C(C)(C)C)cc1-c1ccccc1)c1ccc4c(sc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1cc2c(cc14)C(C)(C)CCC2(C)C]

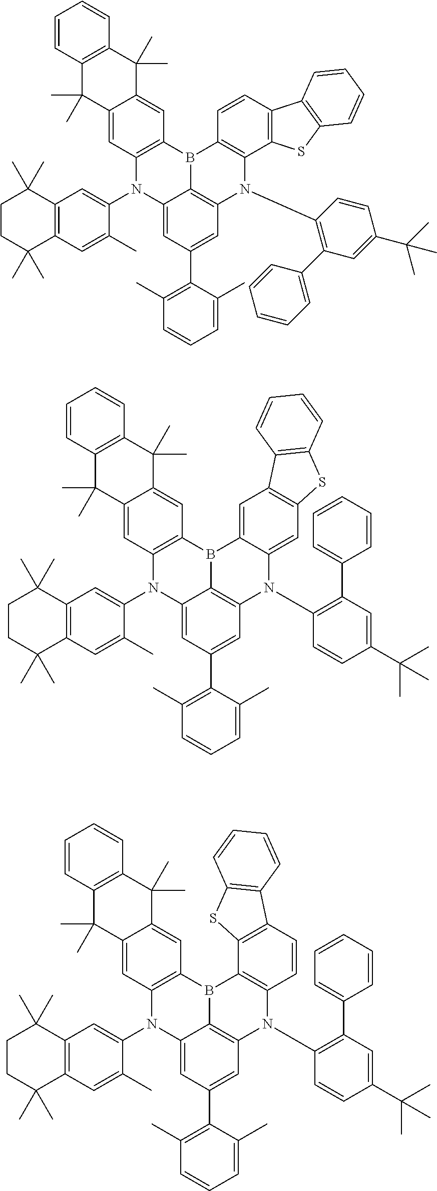 [SMILES: Cc1cc2c(cc1N1c3cc4c(cc3B3c5ccc6c(sc7ccccc76)c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1ccccc16)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(sc6ccccc65)c13)C(C)(C)c1ccccc1C4(C)C)C(C)(C)CCC2(C)C]

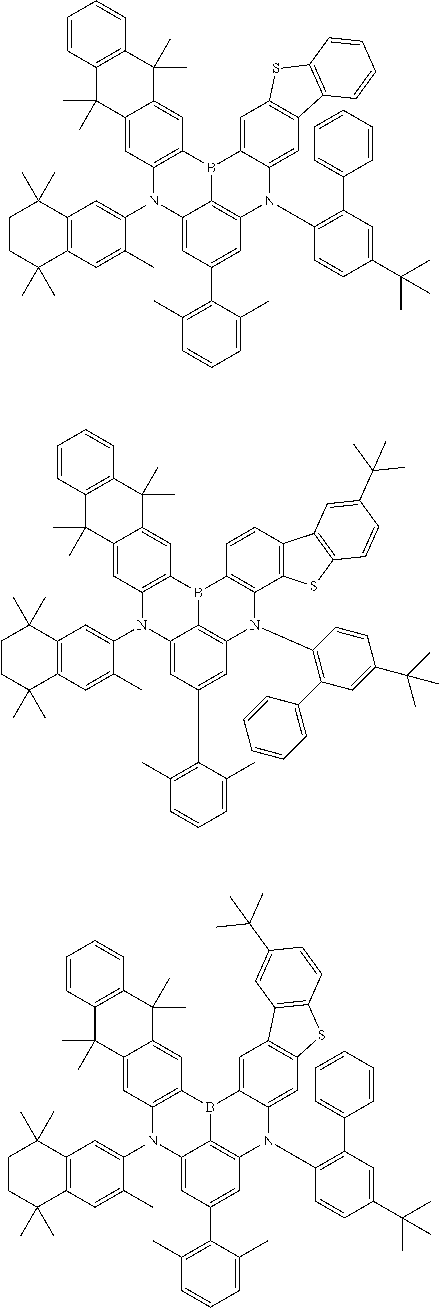 [SMILES: Cc1cc2c(cc1N1c3cc4c(cc3B3c5cc6sc7ccccc7c6cc5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1ccc(C(C)(C)C)cc16)C(C)(C)c1ccccc1C4(C)C)C(C)(C)CCC2(C)C]

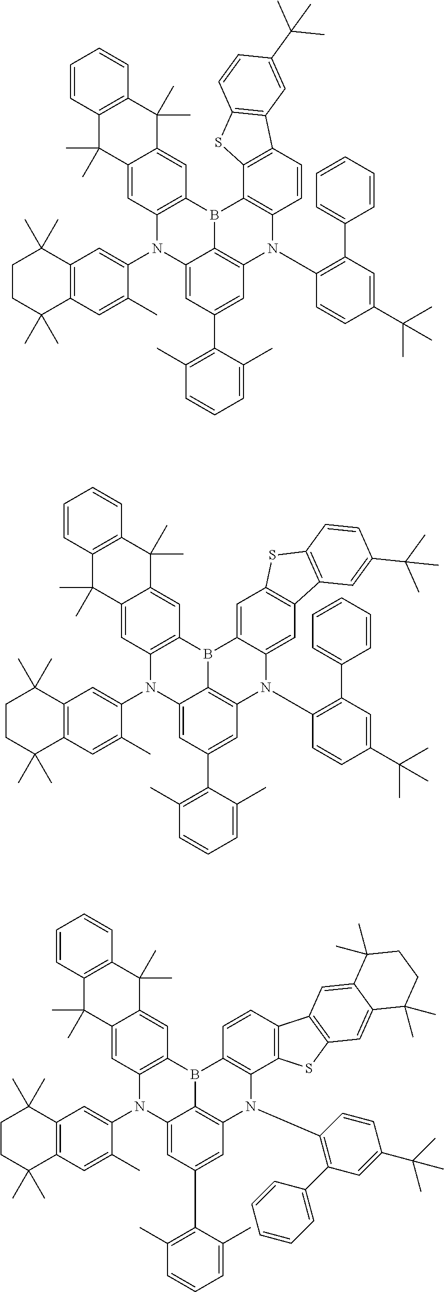 [SMILES: Cc1cc2c(cc1N1c3cc4c(cc3B3c5c1cc(-c1c(C)cccc1C)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C]

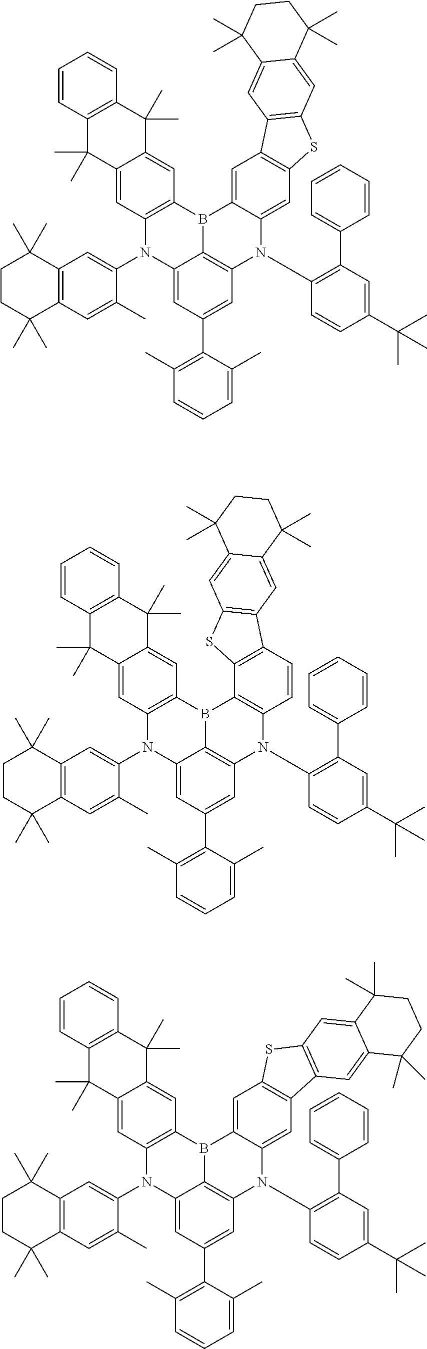 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5ccc(C(C)(C)C)cc5-c5ccccc5)c5cc(-c6c(C)cccc6C)cc1c53)C(C)(C)CCC8(C)C)C(C)(C)c1ccccc1C4(C)C)C(C)(C)CCC2(C)C]

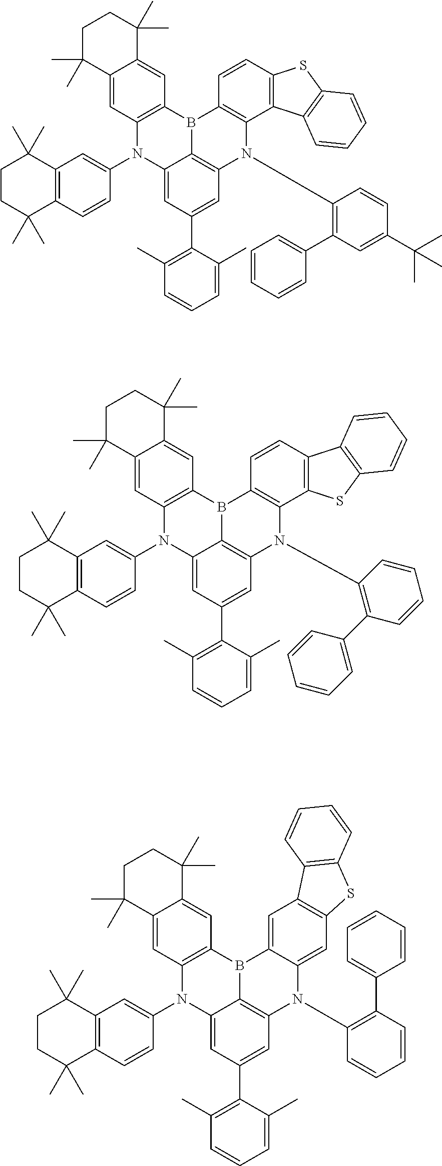 [SMILES: Cc1cccc(C)c1-c1cc2c3c(c1)N(c1ccc(C(C)(C)C)cc1-c1ccccc1)c1c(ccc4sc5ccccc5c14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1c(ccc4c1sc1ccccc14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1cc4sc5ccccc5c4cc1B3c1cc3c(cc1N2c1ccc2c(c1)C(C)(C)CCC2(C)C)C(C)(C)CCC3(C)C]

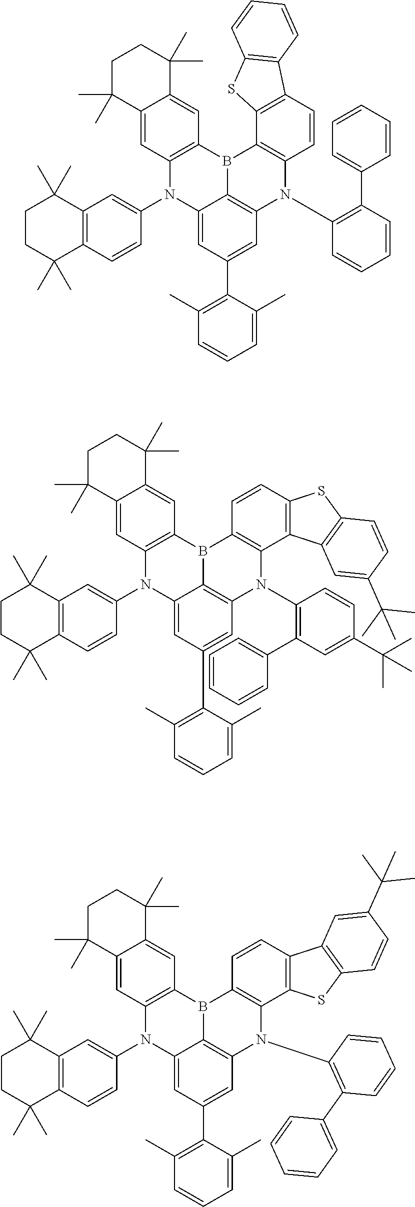 [SMILES: Cc1cccc(C)c1-c1cc2c3c(c1)N(c1ccccc1-c1ccccc1)c1ccc4c(sc5ccccc54)c1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1c(ccc4sc5ccc(C(C)(C)C)cc5c14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1c(ccc4c1sc1ccc(C(C)(C)C)cc14)B3c1cc3c(cc1N2c1ccc2c(c1)C(C)(C)CCC2(C)C)C(C)(C)CCC3(C)C]

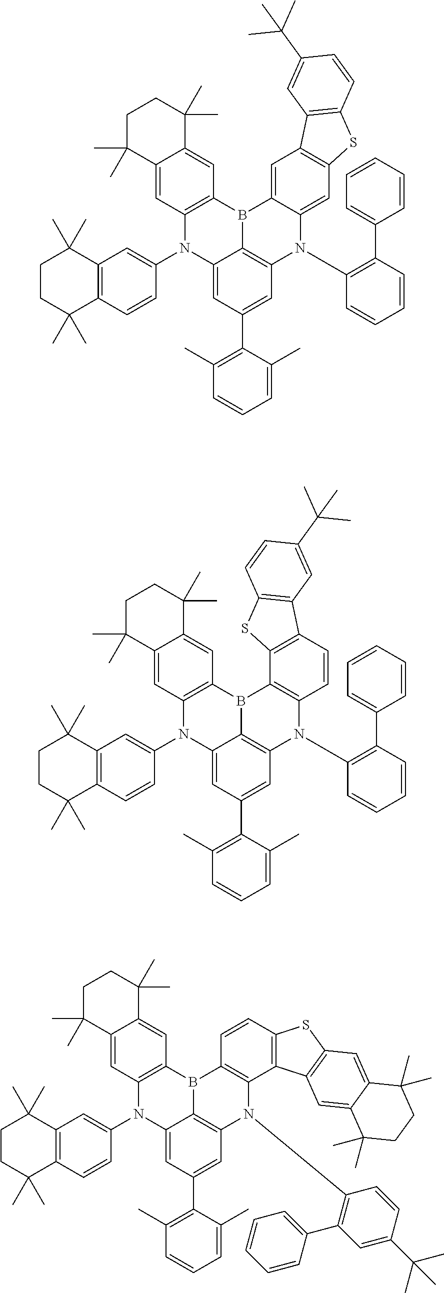 [SMILES: Cc1cccc(C)c1-c1cc2c3c(c1)N(c1ccccc1-c1ccccc1)c1cc4sc5ccc(C(C)(C)C)cc5c4cc1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1ccc4c(sc5ccc(C(C)(C)C)cc54)c1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1ccc2c(c1)C(C)(C)CCC2(C)C)C(C)(C)CCC3(C)C]

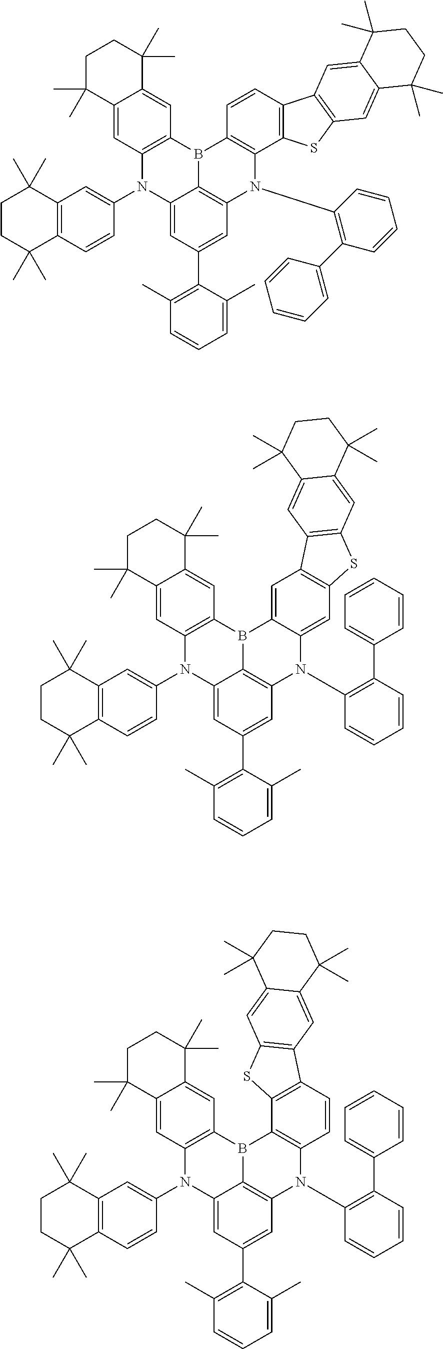 [SMILES: Cc1cccc(C)c1-c1cc2c3c(c1)N(c1ccccc1-c1ccccc1)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1cc4sc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1cccc(C)c1-c1cc2c3c(c1)N(c1ccccc1-c1ccccc1)c1ccc4c(sc5cc6c(cc54)C(C)(C)CCC6(C)C)c1B3c1cc3c(cc1N2c1ccc2c(c1)C(C)(C)CCC2(C)C)C(C)(C)CCC3(C)C]

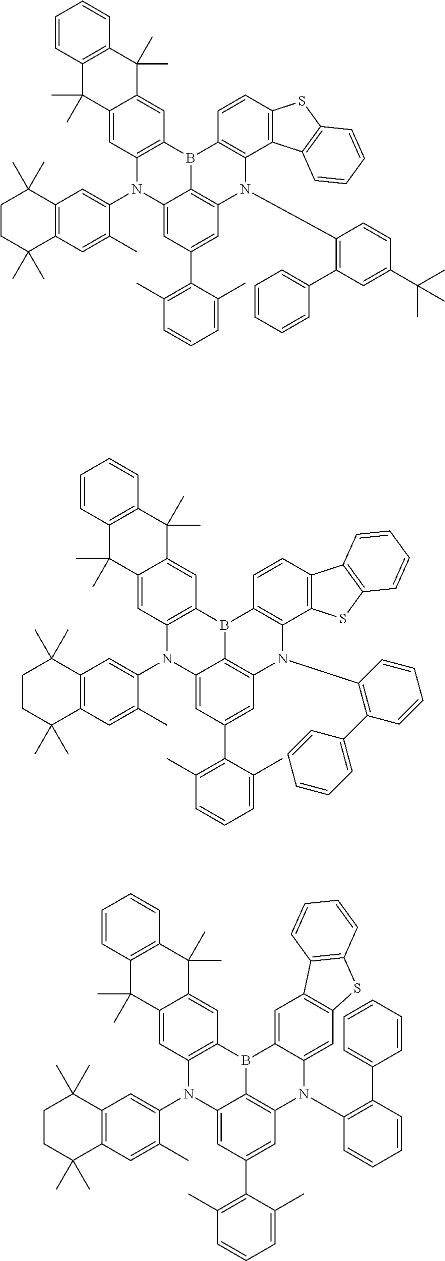 [SMILES: Cc1cc2c(cc1N1c3cc4c(cc3B3c5ccc6sc7ccccc7c6c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)sc1ccccc16)C(C)(C)c1ccccc1C4(C)C)C(C)(C)CCC2(C)C]

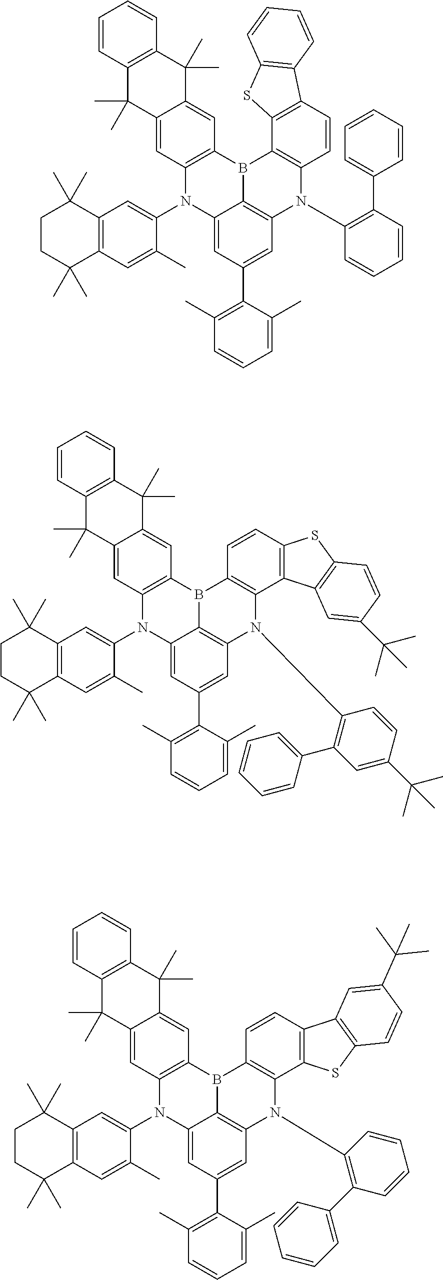 [SMILES: Cc1cc2c(cc1N1c3cc4c(cc3B3c5c1cc(-c1c(C)cccc1C)cc5N(c1ccccc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(-c6c(C)cccc6C)cc1c53)C(C)(C)c1ccccc1C4(C)C)C(C)(C)CCC2(C)C]

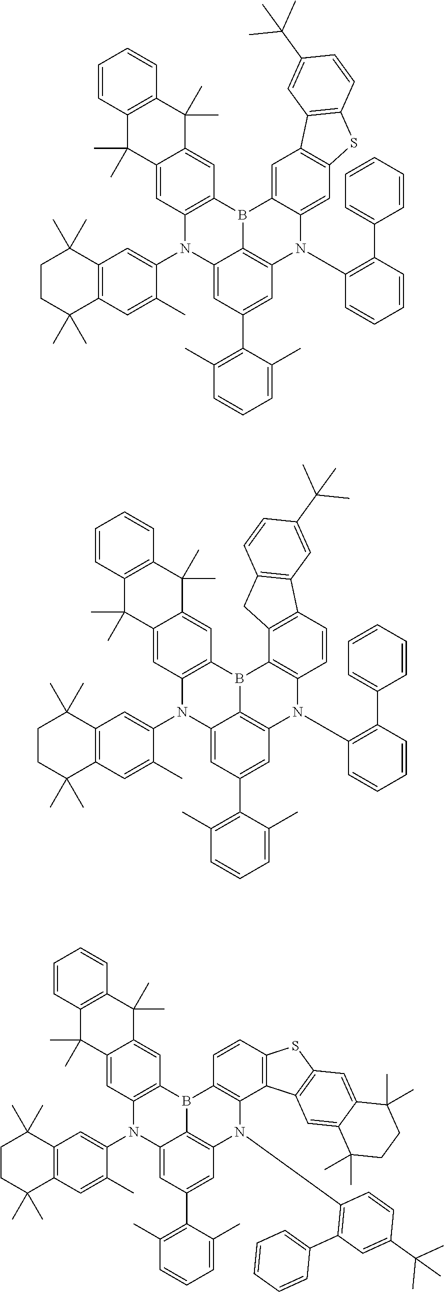 [SMILES: Cc1cc2c(cc1N1c3cc4c(cc3B3c5cc6c(cc5N(c5ccccc5-c5ccccc5)c5cc(-c7c(C)cccc7C)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(c13)Cc1ccc(C(C)(C)C)cc1-5)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(-c6c(C)cccc6C)cc1c53)C(C)(C)CCC8(C)C)C(C)(C)c1ccccc1C4(C)C)C(C)(C)CCC2(C)C]

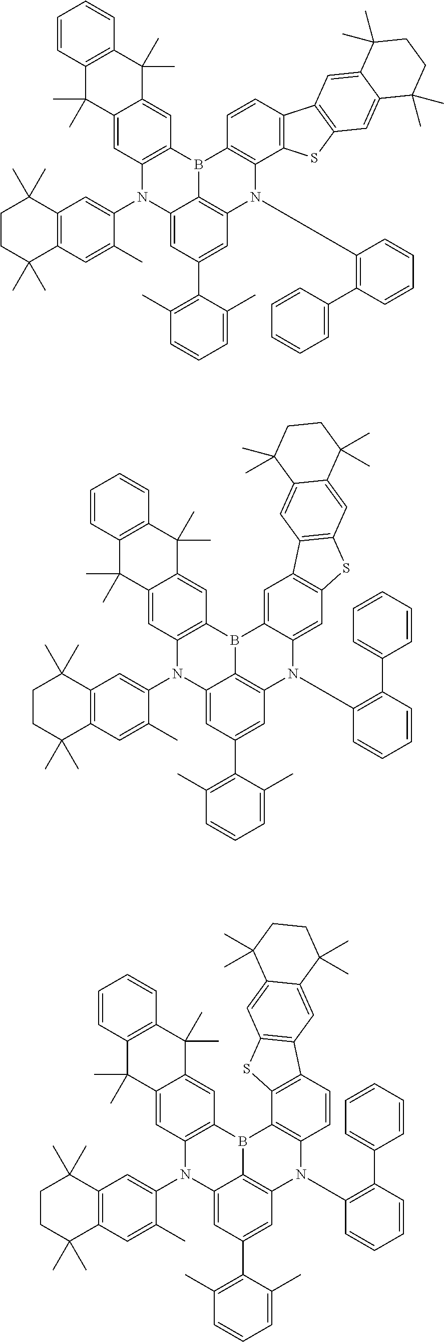 [SMILES: Cc1cc2c(cc1N1c3cc4c(cc3B3c5ccc6c(sc7cc8c(cc76)C(C)(C)CCC8(C)C)c5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(sc6cc7c(cc65)C(C)(C)CCC7(C)C)c13)C(C)(C)c1ccccc1C4(C)C)C(C)(C)CCC2(C)C]

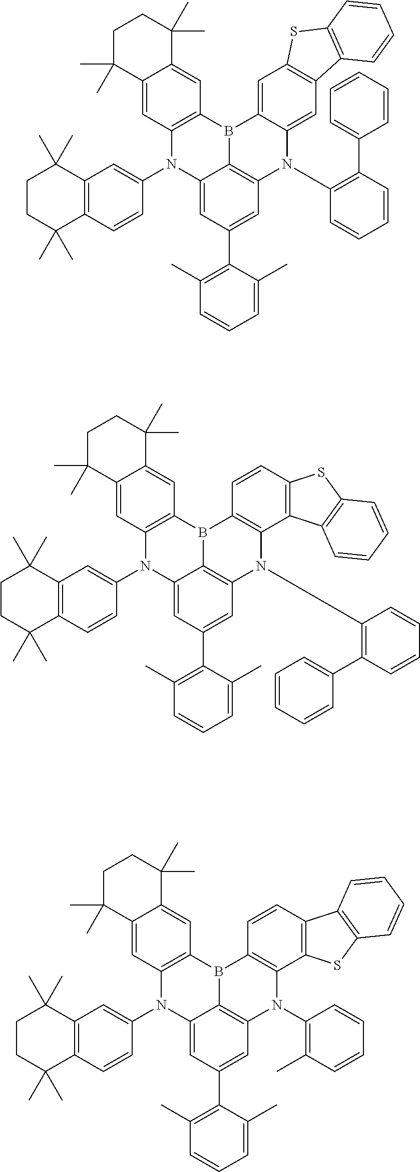 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1ccccc14 ; Cc1cccc(C)c1-c1cc2c3c(c1)N(c1ccccc1-c1ccccc1)c1c(ccc4sc5ccccc5c14)B3c1cc3c(cc1N2c1ccc2c(c1)C(C)(C)CCC2(C)C)C(C)(C)CCC3(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(sc4ccccc43)c21]

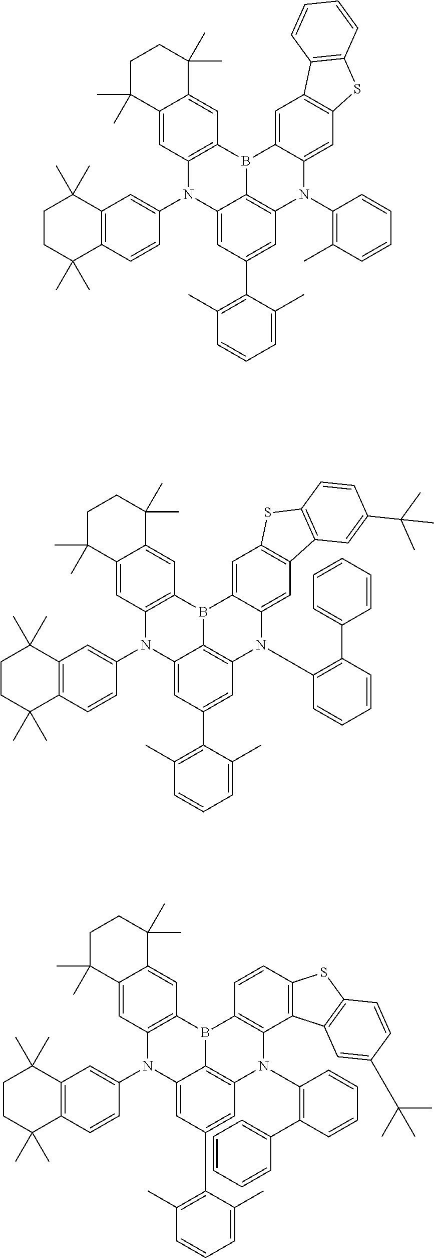 [SMILES: Cc1ccccc1N1c2cc3sc4ccccc4c3cc2B2c3cc4c(cc3N(c3ccc5c(c3)C(C)(C)CCC5(C)C)c3cc(-c5c(C)cccc5C)cc1c32)C(C)(C)CCC4(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1ccc(C(C)(C)C)cc14 ; Cc1cccc(C)c1-c1cc2c3c(c1)N(c1ccccc1-c1ccccc1)c1c(ccc4sc5ccc(C(C)(C)C)cc5c14)B3c1cc3c(cc1N2c1ccc2c(c1)C(C)(C)CCC2(C)C)C(C)(C)CCC3(C)C]

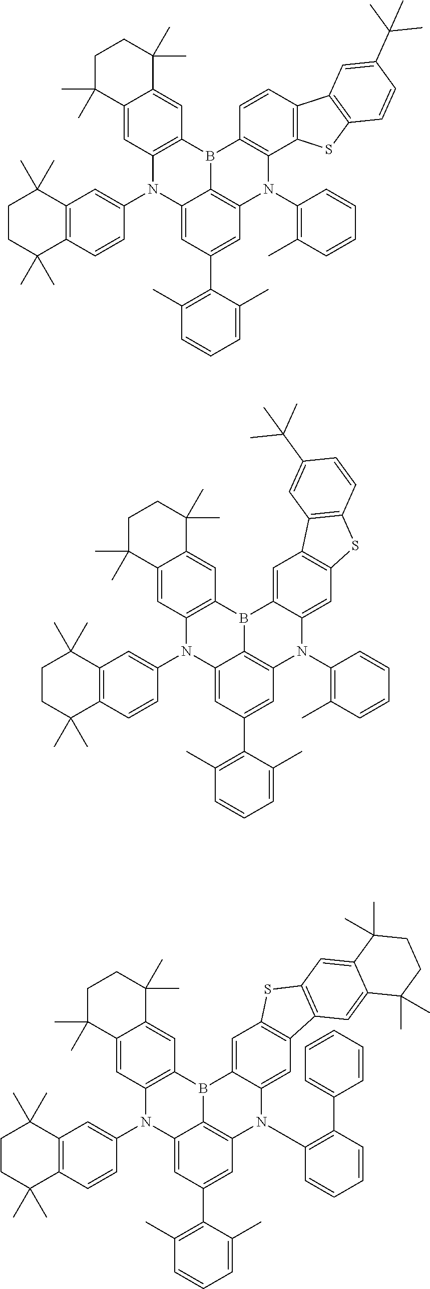 [SMILES: Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(sc4ccc(C(C)(C)C)cc43)c21 ; Cc1ccccc1N1c2cc3sc4ccc(C(C)(C)C)cc4c3cc2B2c3cc4c(cc3N(c3ccc5c(c3)C(C)(C)CCC5(C)C)c3cc(-c5c(C)cccc5C)cc1c32)C(C)(C)CCC4(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1cc2c(cc14)C(C)(C)CCC2(C)C]

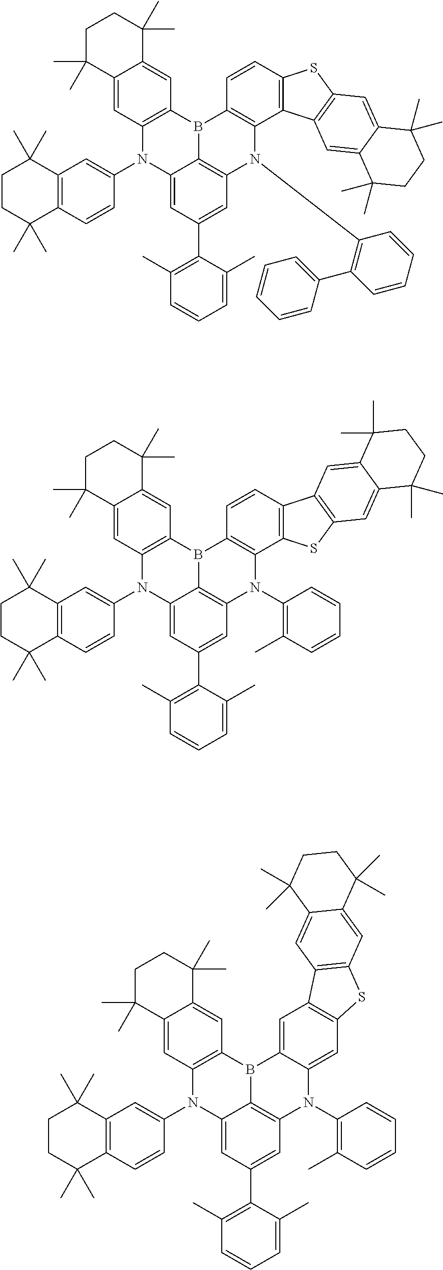 [SMILES: Cc1cccc(C)c1-c1cc2c3c(c1)N(c1ccccc1-c1ccccc1)c1c(ccc4sc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(sc4cc5c(cc43)C(C)(C)CCC5(C)C)c21 ; Cc1ccccc1N1c2cc3sc4cc5c(cc4c3cc2B2c3cc4c(cc3N(c3ccc6c(c3)C(C)(C)CCC6(C)C)c3cc(-c6c(C)cccc6C)cc1c32)C(C)(C)CCC4(C)C)C(C)(C)CCC5(C)C]

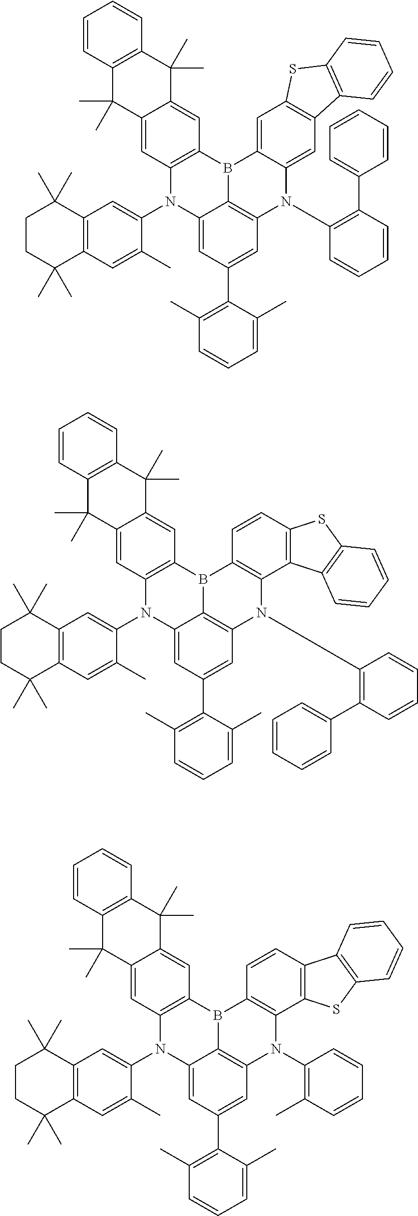 [SMILES: Cc1cc2c(cc1N1c3cc4c(cc3B3c5cc6sc7ccccc7c6cc5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5C)c5cc(-c6c(C)cccc6C)cc1c53)C(C)(C)c1ccccc1C4(C)C)C(C)(C)CCC2(C)C]

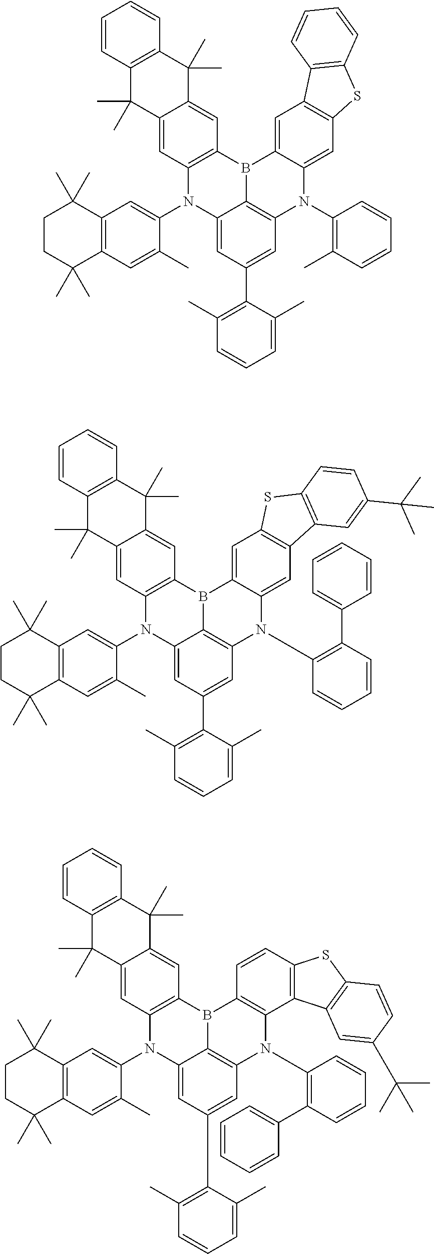 [SMILES: Cc1ccccc1N1c2cc3sc4ccccc4c3cc2B2c3cc4c(cc3N(c3cc5c(cc3C)C(C)(C)CCC5(C)C)c3cc(-c5c(C)cccc5C)cc1c32)C(C)(C)c1ccccc1C4(C)C ; Cc1cc2c(cc1N1c3cc4c(cc3B3c5cc6sc7ccc(C(C)(C)C)cc7c6cc5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(-c6c(C)cccc6C)cc1c53)C(C)(C)c1ccccc1C4(C)C)C(C)(C)CCC2(C)C]

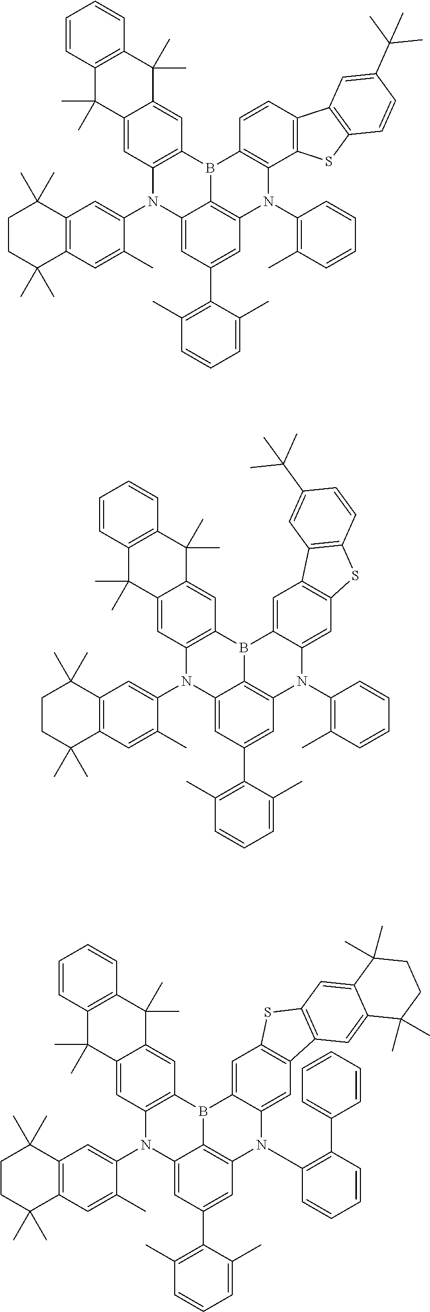 [SMILES: Cc1cc2c(cc1N1c3cc4c(cc3B3c5ccc6c(sc7ccc(C(C)(C)C)cc76)c5N(c5ccccc5C)c5cc(-c6c(C)cccc6C)cc1c53)C(C)(C)c1ccccc1C4(C)C)C(C)(C)CCC2(C)C ; Cc1ccccc1N1c2cc3sc4ccc(C(C)(C)C)cc4c3cc2B2c3cc4c(cc3N(c3cc5c(cc3C)C(C)(C)CCC5(C)C)c3cc(-c5c(C)cccc5C)cc1c32)C(C)(C)c1ccccc1C4(C)C ; Cc1cc2c(cc1N1c3cc4c(cc3B3c5cc6sc7cc8c(cc7c6cc5N(c5ccccc5-c5ccccc5)c5cc(-c6c(C)cccc6C)cc1c53)C(C)(C)CCC8(C)C)C(C)(C)c1ccccc1C4(C)C)C(C)(C)CCC2(C)C]

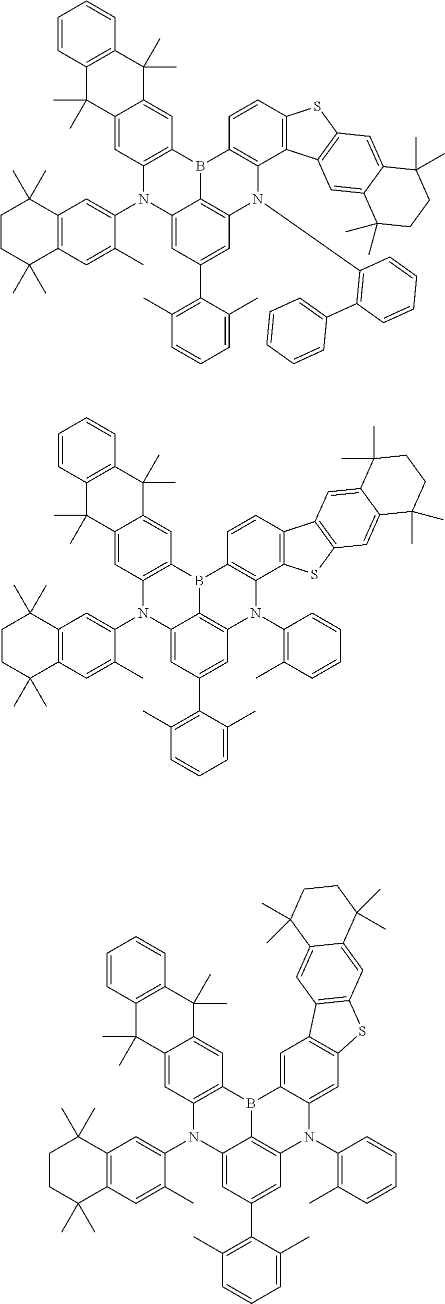 [SMILES: Cc1cc2c(cc1N1c3cc4c(cc3B3c5ccc6sc7cc8c(cc7c6c5N(c5ccccc5-c5ccccc5)c5cc(-c6c(C)cccc6C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(-c6c(C)cccc6C)cc1c53)C(C)(C)c1ccccc1C4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(-c6c(C)cccc6C)cc1c32)C(C)(C)c1ccccc1C4(C)C)C(C)(C)CCC5(C)C]

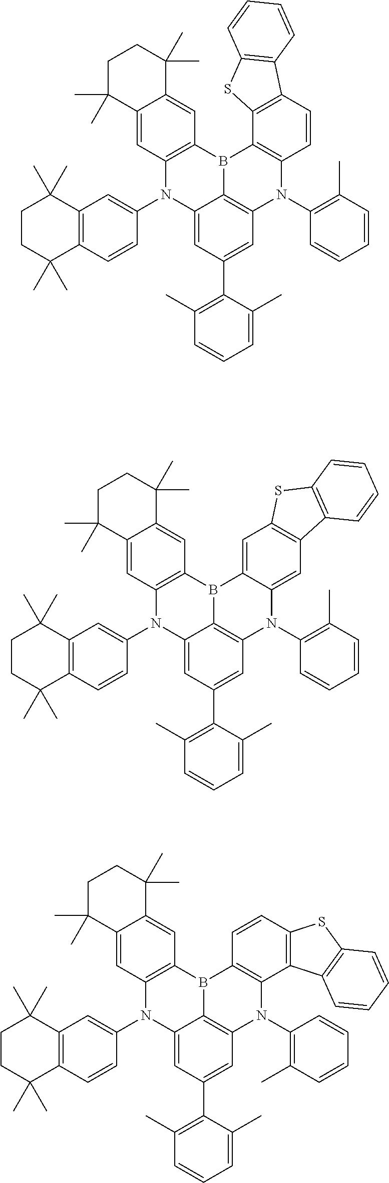 [SMILES: Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2c1ccc1c2sc2ccccc21 ; Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)sc1ccccc13 ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3sc4ccccc4c3c21]

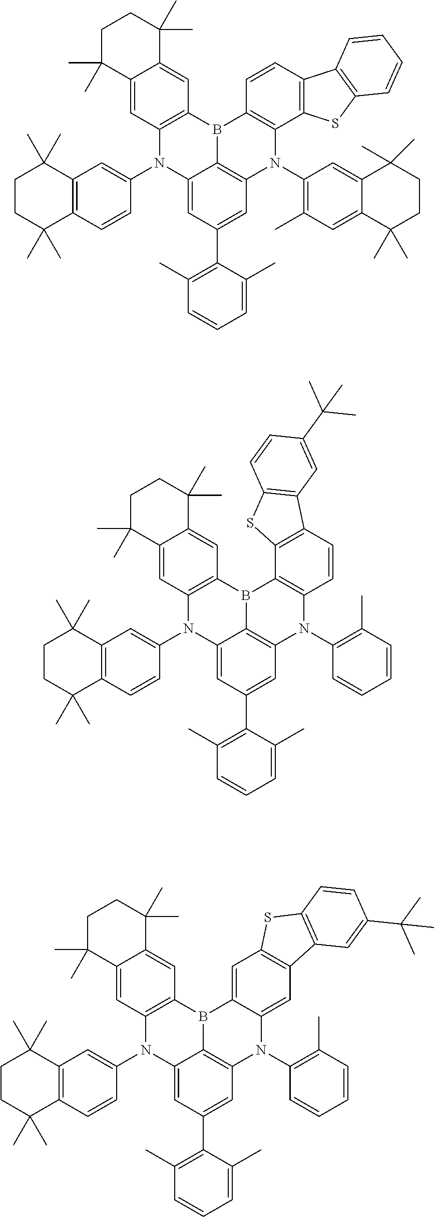 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5ccccc54)c31)C(C)(C)CCC2(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2c1ccc1c2sc2ccc(C(C)(C)C)cc21 ; Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)sc1ccc(C(C)(C)C)cc13]

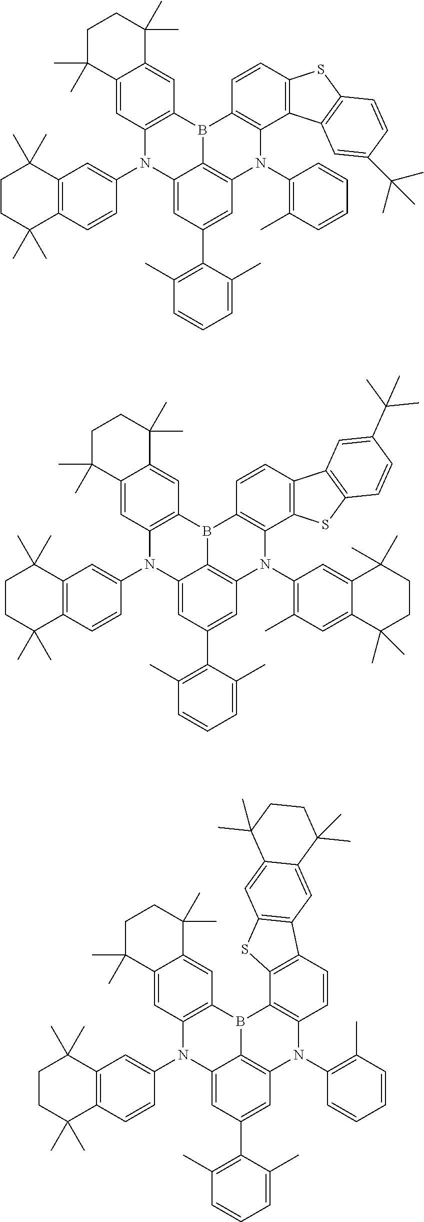 [SMILES: Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3sc4ccc(C(C)(C)C)cc4c3c21 ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5ccc(C(C)(C)C)cc54)c31)C(C)(C)CCC2(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2c1ccc1c2sc2cc3c(cc21)C(C)(C)CCC3(C)C]

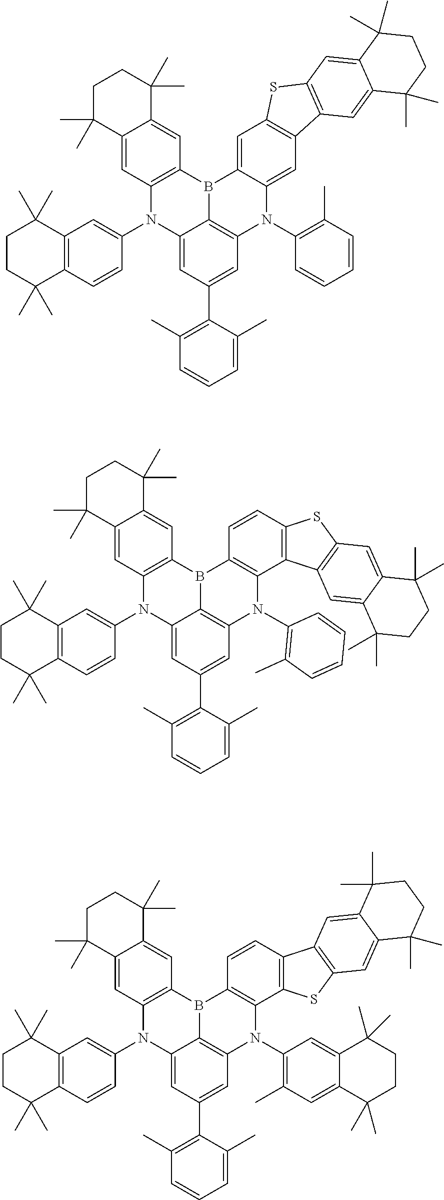 [SMILES: Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)sc1cc2c(cc13)C(C)(C)CCC2(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3sc4cc5c(cc4c3c21)C(C)(C)CCC5(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5cc6c(cc54)C(C)(C)CCC6(C)C)c31)C(C)(C)CCC2(C)C]

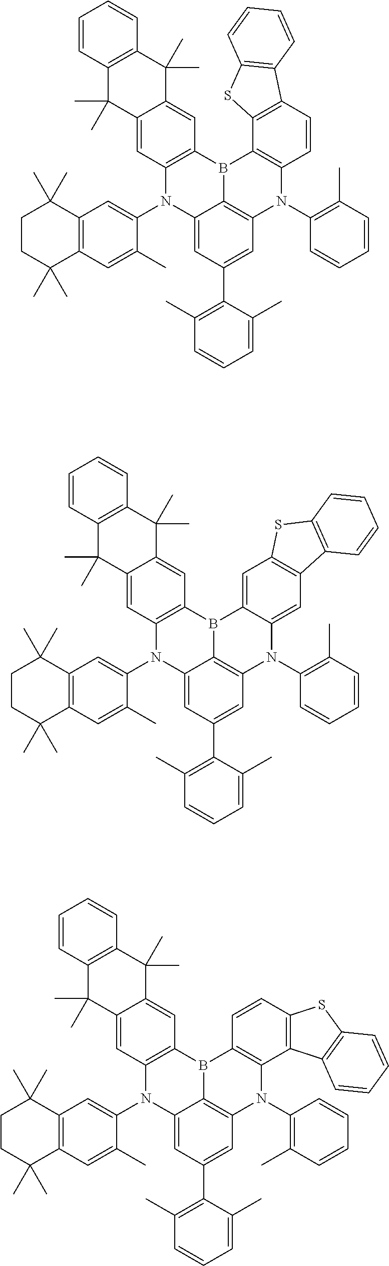 [SMILES: Cc1cc2c(cc1N1c3cc4c(cc3B3c5c1cc(-c1c(C)cccc1C)cc5N(c1ccccc1C)c1ccc5c(sc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)sc1ccccc13 ; Cc1cc2c(cc1N1c3cc4c(cc3B3c5ccc6sc7ccccc7c6c5N(c5ccccc5C)c5cc(-c6c(C)cccc6C)cc1c53)C(C)(C)c1ccccc1C4(C)C)C(C)(C)CCC2(C)C]

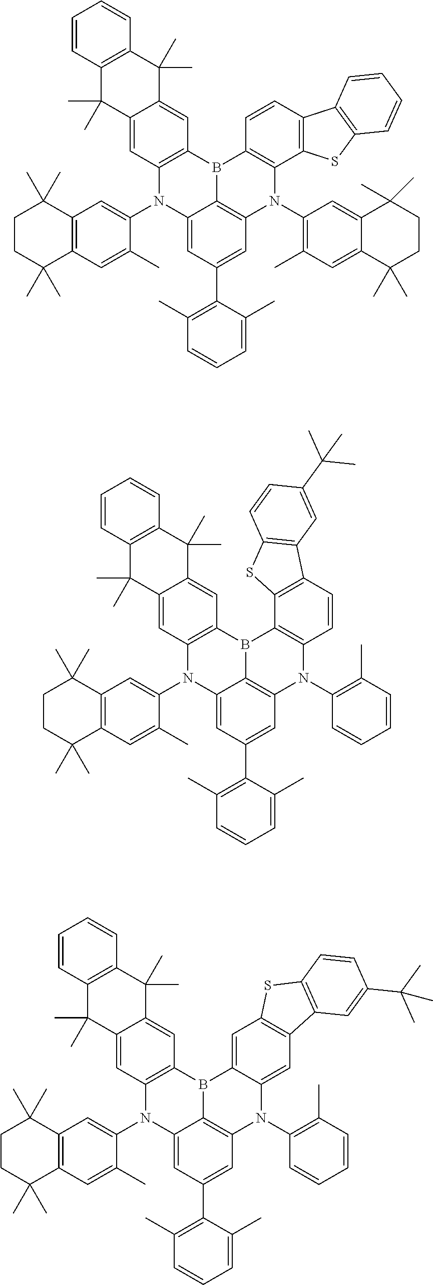 [SMILES: Cc1cc2c(cc1N1c3cc4c(cc3B3c5ccc6c(sc7ccccc76)c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(sc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)sc1ccc(C(C)(C)C)cc13]

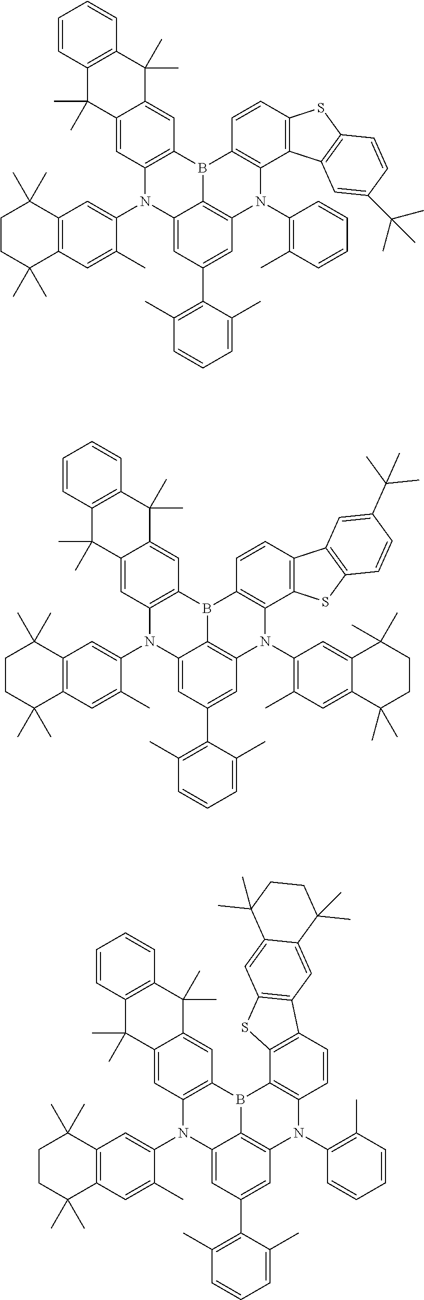 [SMILES: Cc1cc2c(cc1N1c3cc4c(cc3B3c5ccc6sc7ccc(C(C)(C)C)cc7c6c5N(c5ccccc5C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(sc6cc7c(cc65)C(C)(C)CCC7(C)C)c13)C(C)(C)c1ccccc1C4(C)C)C(C)(C)CCC2(C)C]

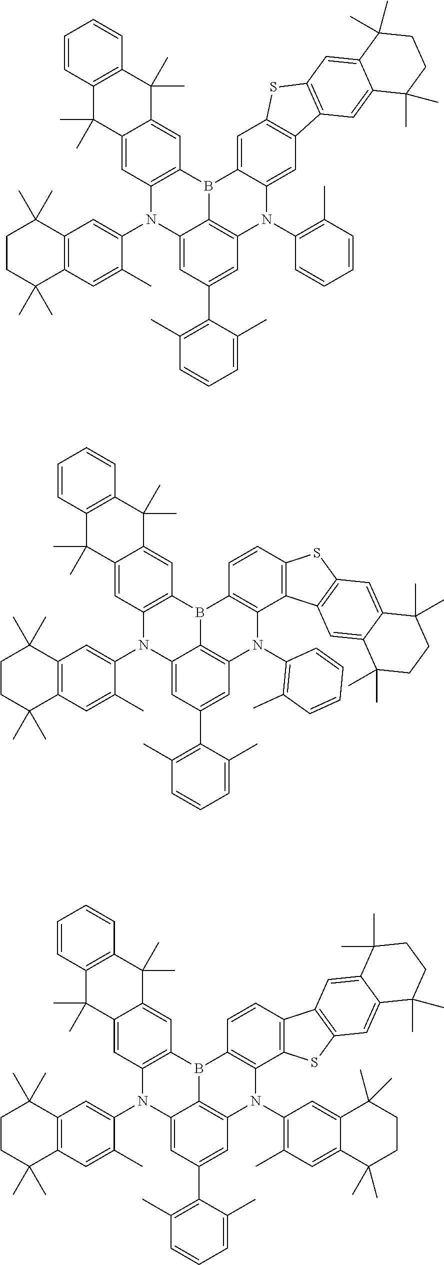 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(-c6c(C)cccc6C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C]

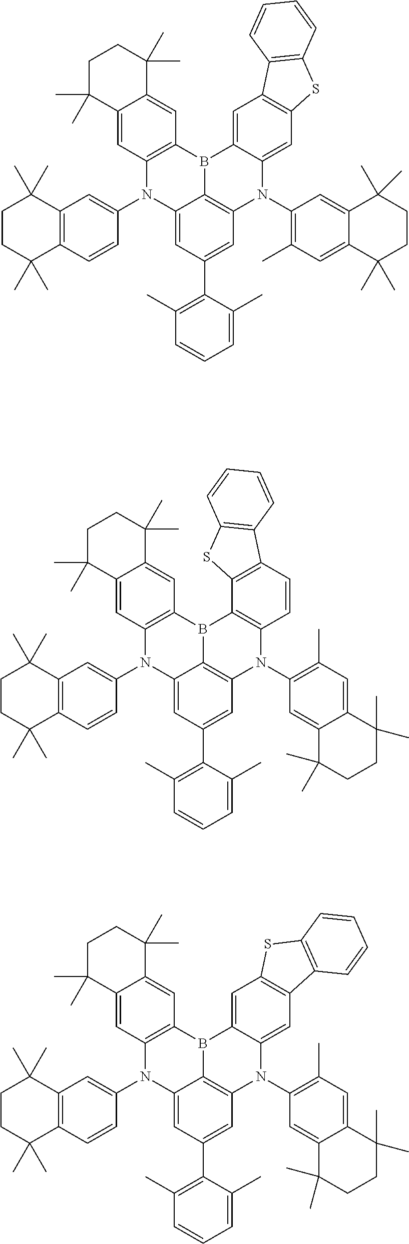 [SMILES: Cc1cc2c(cc1N1c3cc4sc5ccccc5c4cc3B3c4cc5c(cc4N(c4ccc6c(c4)C(C)(C)CCC6(C)C)c4cc(-c6c(C)cccc6C)cc1c43)C(C)(C)CCC5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3sc3ccccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)sc1ccccc14)C(C)(C)CCC2(C)C]

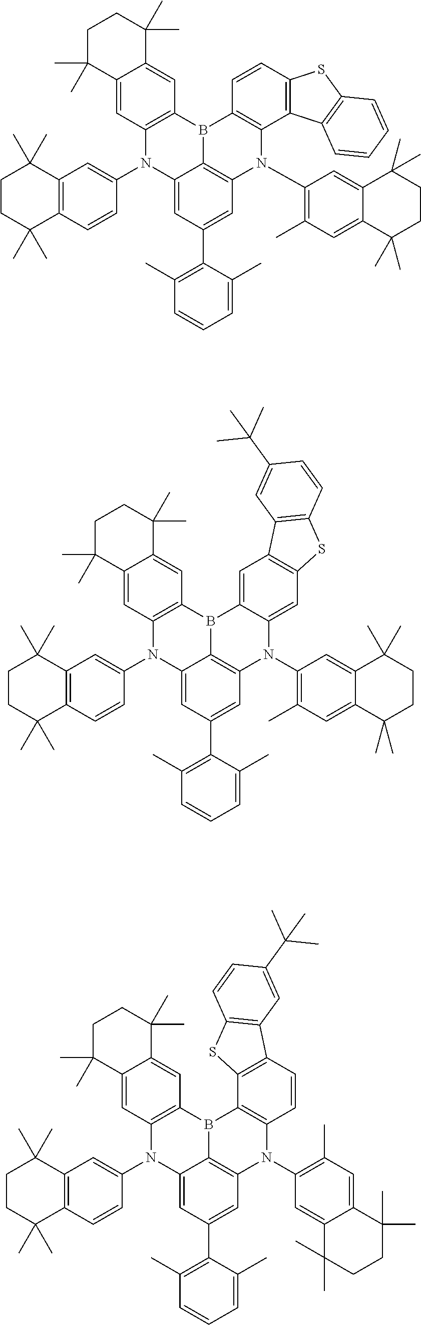 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4sc5ccccc5c4c31)C(C)(C)CCC2(C)C ; Cc1cc2c(cc1N1c3cc4sc5ccc(C(C)(C)C)cc5c4cc3B3c4cc5c(cc4N(c4ccc6c(c4)C(C)(C)CCC6(C)C)c4cc(-c6c(C)cccc6C)cc1c43)C(C)(C)CCC5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3sc3ccc(C(C)(C)C)cc31)C(C)(C)CCC2(C)C]

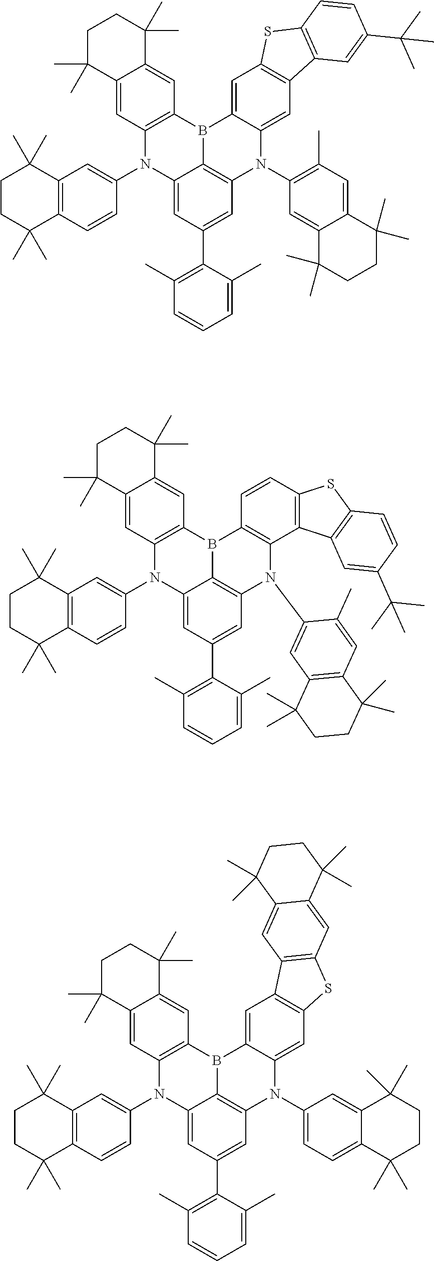 [SMILES: Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)sc1ccc(C(C)(C)C)cc14)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4sc5ccc(C(C)(C)C)cc5c4c31)C(C)(C)CCC2(C)C ; Cc1cccc(C)c1-c1cc2c3c(c1)N(c1ccc4c(c1)C(C)(C)CCC4(C)C)c1cc4sc5cc6c(cc5c4cc1B3c1cc3c(cc1N2c1ccc2c(c1)C(C)(C)CCC2(C)C)C(C)(C)CCC3(C)C)C(C)(C)CCC6(C)C]

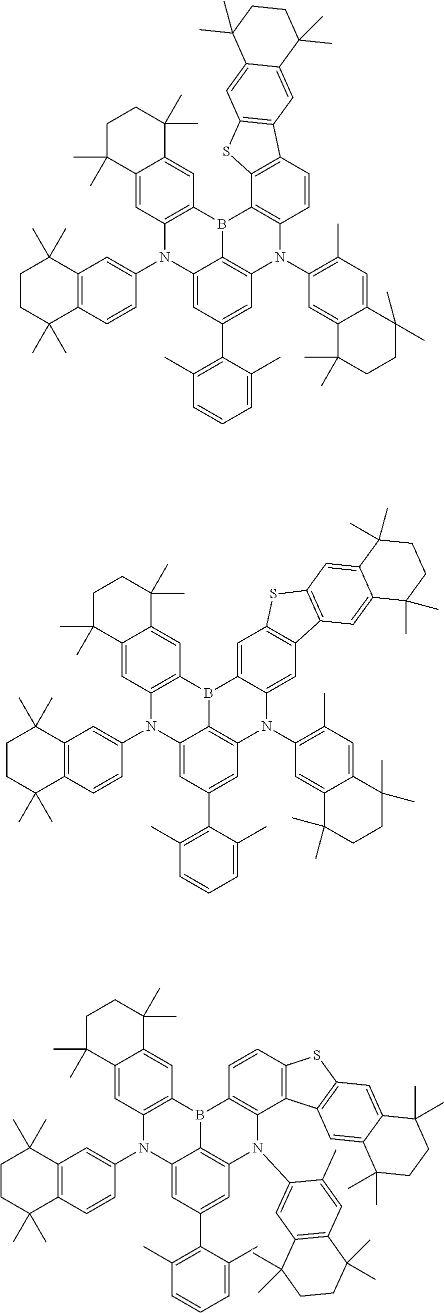 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3sc3cc4c(cc31)C(C)(C)CCC4(C)C)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)sc1cc3c(cc14)C(C)(C)CCC3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4sc5cc6c(cc5c4c31)C(C)(C)CCC6(C)C)C(C)(C)CCC2(C)C]

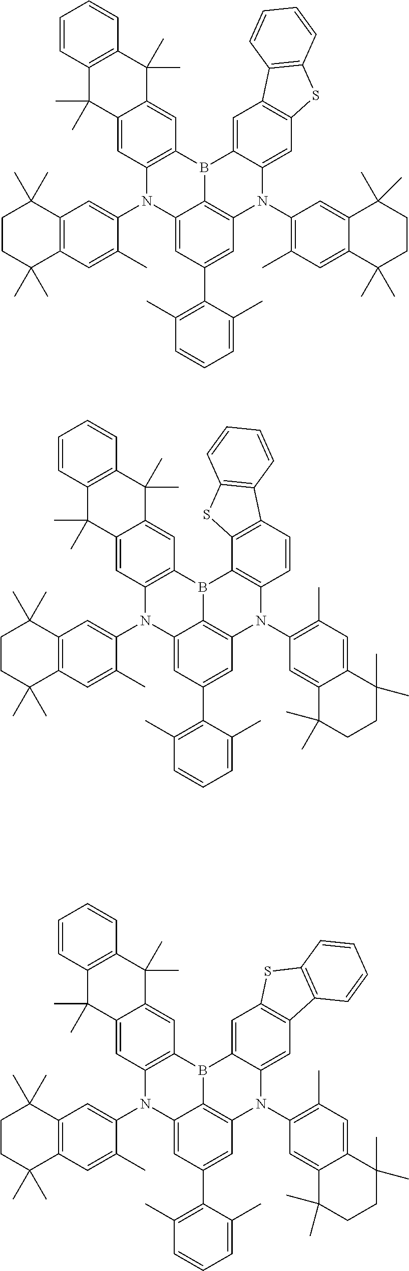 [SMILES: Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)sc1ccccc16)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1cc5c(cc1C)C(C)(C)CCC5(C)C)c1ccc5c(sc6ccccc65)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C]

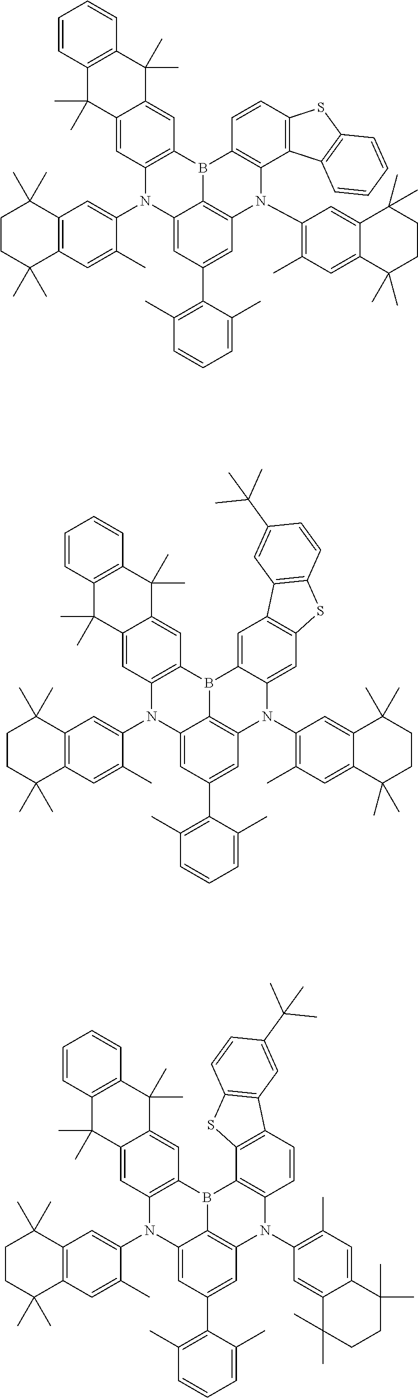 [SMILES: Cc1cc2c(cc1N1c3cc4c(cc3B3c5ccc6sc7ccccc7c6c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1cc5c(cc1C)C(C)(C)CCC5(C)C)c1ccc5c(sc6ccc(C(C)(C)C)cc65)c13)C(C)(C)c1ccccc1C4(C)C)C(C)(C)CCC2(C)C]

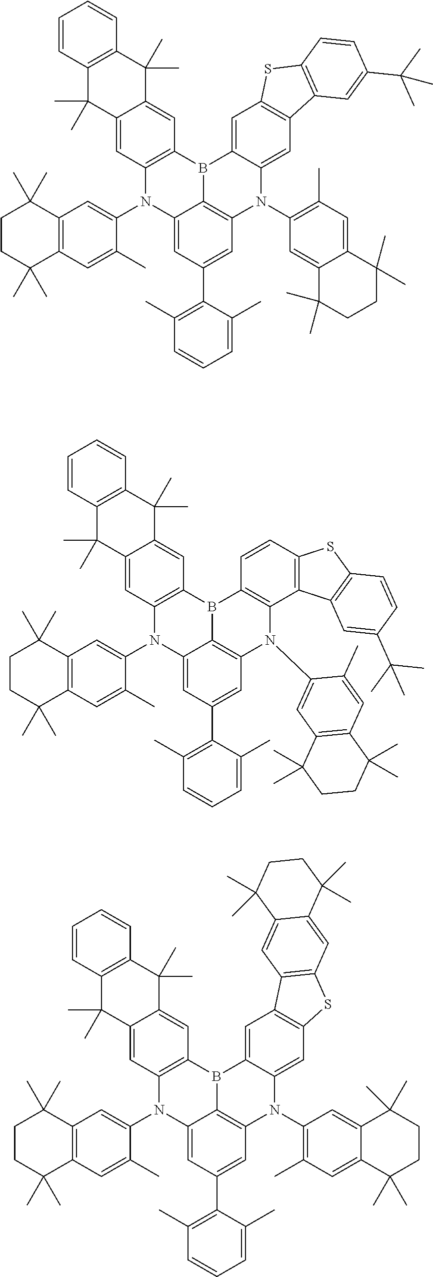 [SMILES: Cc1cc2c(cc1N1c3cc4c(cc3B3c5cc6sc7ccc(C(C)(C)C)cc7c6cc5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)sc1cc3c(cc16)C(C)(C)CCC3(C)C)C(C)(C)c1ccccc1C4(C)C)C(C)(C)CCC2(C)C]

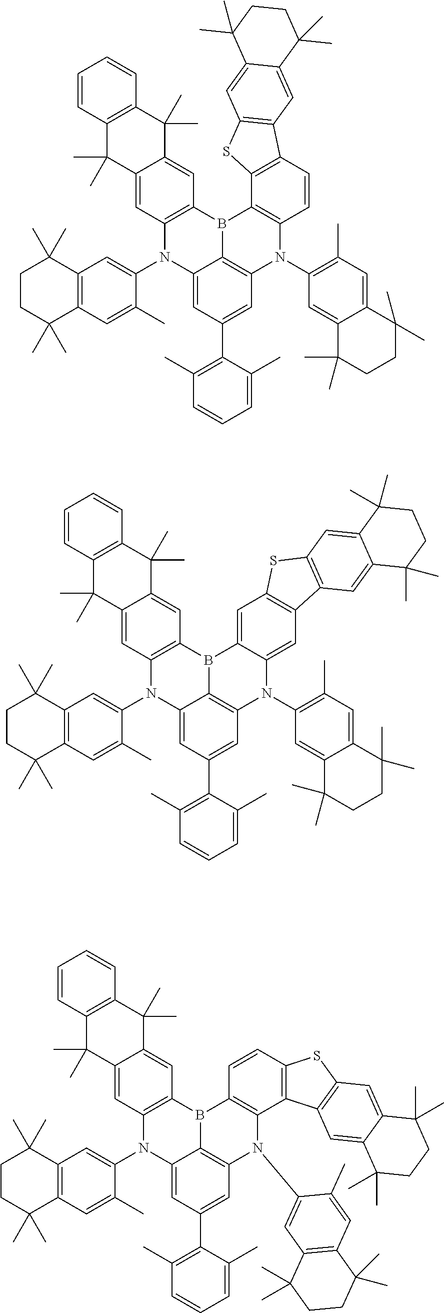 [SMILES: Cc1cc2c(cc1N1c3cc4c(cc3B3c5c1cc(-c1c(C)cccc1C)cc5N(c1cc5c(cc1C)C(C)(C)CCC5(C)C)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5cc6c(cc5C)C(C)(C)CCC6(C)C)c5cc(-c6c(C)cccc6C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5cc6c(cc5C)C(C)(C)CCC6(C)C)c5cc(-c6c(C)cccc6C)cc1c53)C(C)(C)CCC8(C)C)C(C)(C)c1ccccc1C4(C)C)C(C)(C)CCC2(C)C]

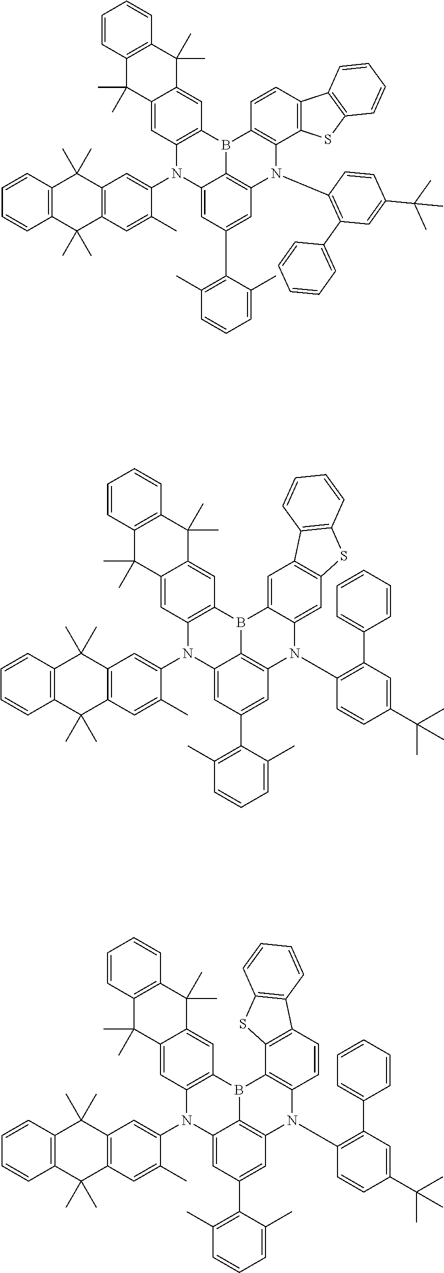 [SMILES: Cc1cc2c(cc1N1c3cc4c(cc3B3c5ccc6c(sc7ccccc76)c5N(c5ccc(C(C)(C)C)cc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1ccccc16)C(C)(C)c1ccccc1C4(C)C)C(C)(C)c1ccccc1C2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(sc6ccccc65)c13)C(C)(C)c1ccccc1C4(C)C)C(C)(C)c1ccccc1C2(C)C]

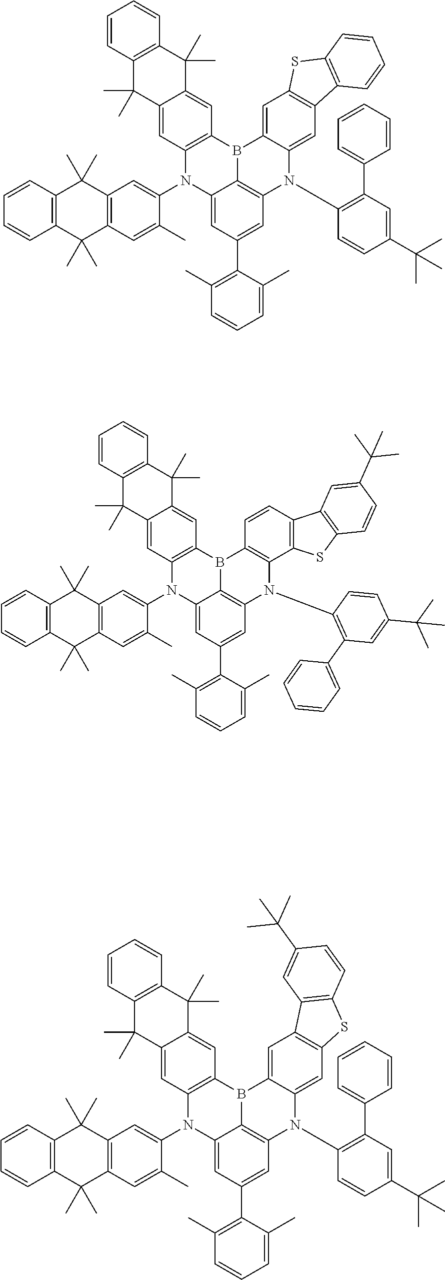 [SMILES: Cc1cc2c(cc1N1c3cc4c(cc3B3c5cc6sc7ccccc7c6cc5N(c5ccc(C(C)(C)C)cc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1ccc(C(C)(C)C)cc16)C(C)(C)c1ccccc1C4(C)C)C(C)(C)c1ccccc1C2(C)C]

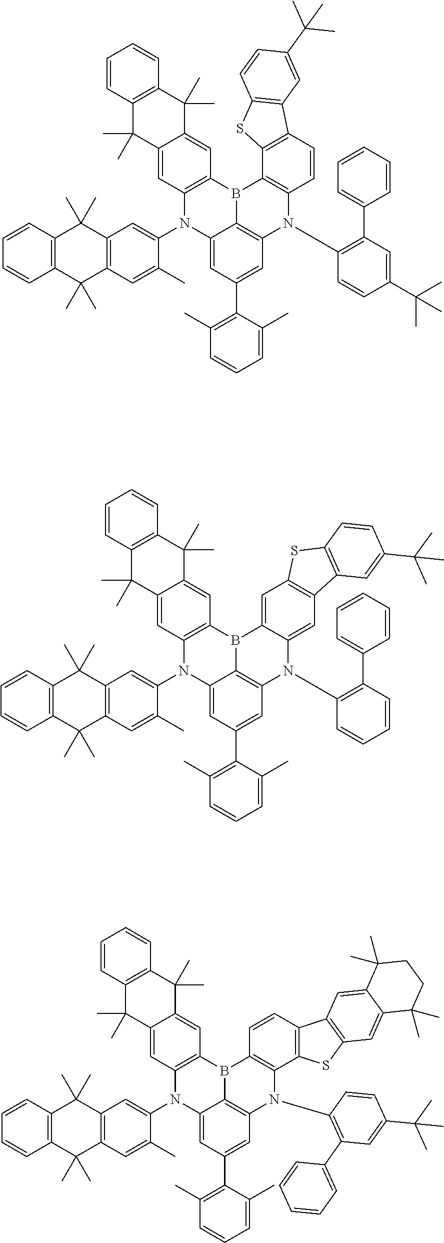 [SMILES: Cc1cc2c(cc1N1c3cc4c(cc3B3c5c1cc(-c1c(C)cccc1C)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)c1ccccc1C2(C)C ; Cc1cc2c(cc1N1c3cc4c(cc3B3c5cc6sc7ccc(C(C)(C)C)cc7c6cc5N(c5ccccc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(-c6c(C)cccc6C)cc1c53)C(C)(C)c1ccccc1C4(C)C)C(C)(C)c1ccccc1C2(C)C]

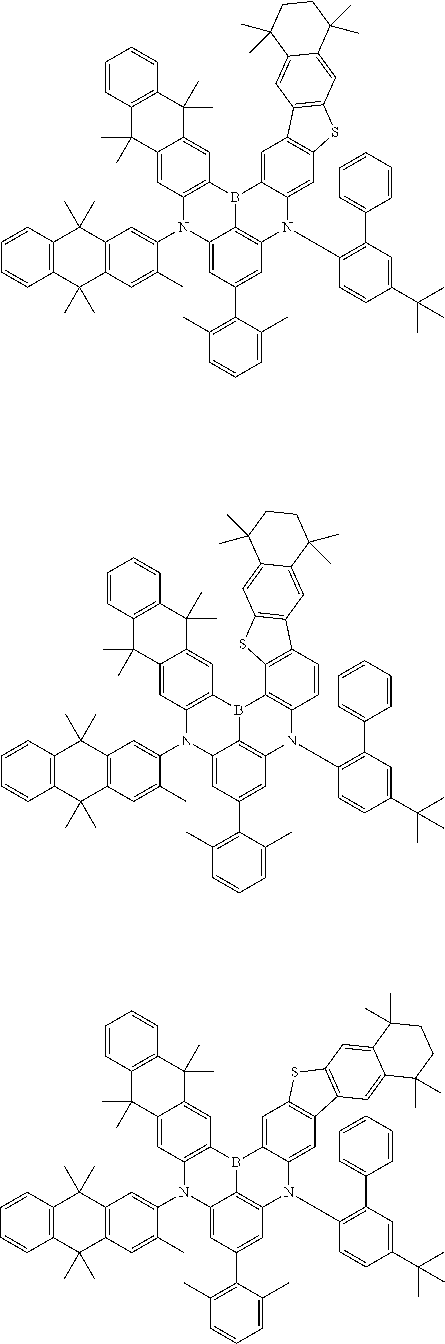 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1cc3c(cc16)C(C)(C)CCC3(C)C)C(C)(C)c1ccccc1C4(C)C)C(C)(C)c1ccccc1C2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(sc6cc7c(cc65)C(C)(C)CCC7(C)C)c13)C(C)(C)c1ccccc1C4(C)C)C(C)(C)c1ccccc1C2(C)C ; Cc1cc2c(cc1N1c3cc4c(cc3B3c5cc6sc7cc8c(cc7c6cc5N(c5ccc(C(C)(C)C)cc5-c5ccccc5)c5cc(-c6c(C)cccc6C)cc1c53)C(C)(C)CCC8(C)C)C(C)(C)c1ccccc1C4(C)C)C(C)(C)c1ccccc1C2(C)C]

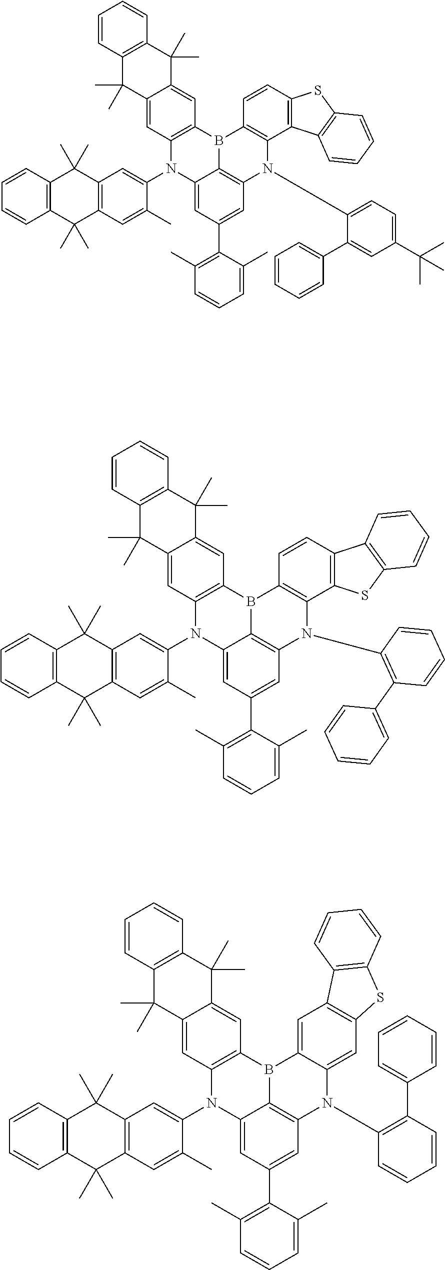 [SMILES: Cc1cc2c(cc1N1c3cc4c(cc3B3c5ccc6sc7ccccc7c6c5N(c5ccc(C(C)(C)C)cc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5ccc6c(sc7ccccc76)c5N(c5ccccc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5cc6c(cc5N(c5ccccc5-c5ccccc5)c5cc(-c7c(C)cccc7C)cc1c53)sc1ccccc16)C(C)(C)c1ccccc1C4(C)C)C(C)(C)c1ccccc1C2(C)C]

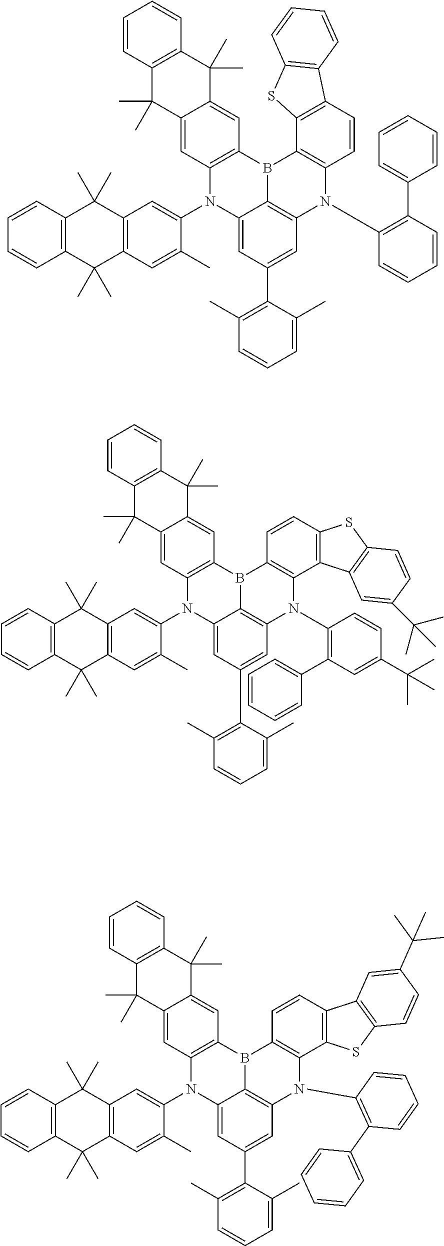 [SMILES: Cc1cc2c(cc1N1c3cc4c(cc3B3c5c1cc(-c1c(C)cccc1C)cc5N(c1ccccc1-c1ccccc1)c1ccc5c(sc6ccccc65)c13)C(C)(C)c1ccccc1C4(C)C)C(C)(C)c1ccccc1C2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5ccc6c(sc7ccc(C(C)(C)C)cc76)c5N(c5ccccc5-c5ccccc5)c5cc(-c6c(C)cccc6C)cc1c53)C(C)(C)c1ccccc1C4(C)C)C(C)(C)c1ccccc1C2(C)C]

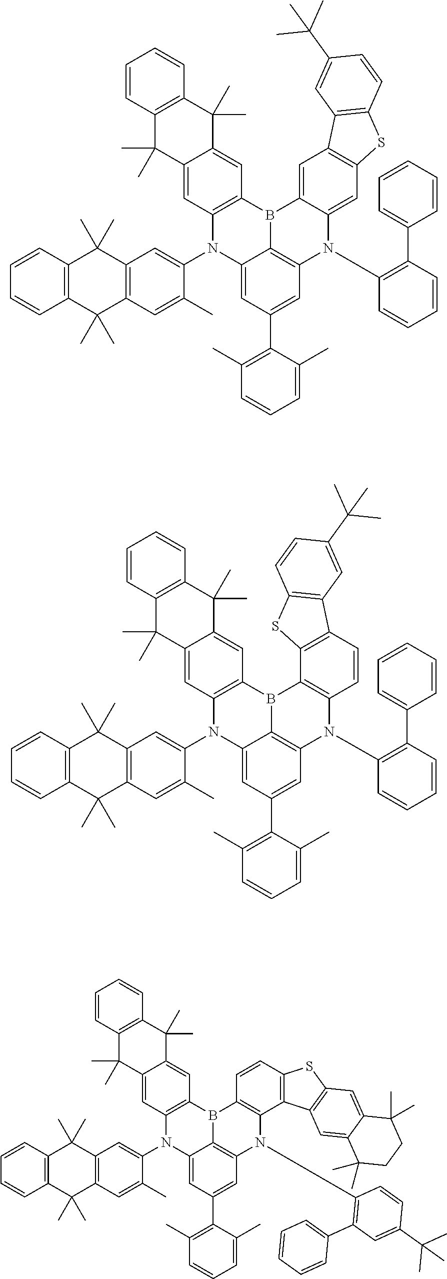 [SMILES: Cc1cc2c(cc1N1c3cc4c(cc3B3c5cc6c(cc5N(c5ccccc5-c5ccccc5)c5cc(-c7c(C)cccc7C)cc1c53)sc1ccc(C(C)(C)C)cc16)C(C)(C)c1ccccc1C4(C)C)C(C)(C)c1ccccc1C2(C)C ; Cc1cc2c(cc1N1c3cc4c(cc3B3c5c1cc(-c1c(C)cccc1C)cc5N(c1ccccc1-c1ccccc1)c1ccc5c(sc6ccc(C(C)(C)C)cc65)c13)C(C)(C)c1ccccc1C4(C)C)C(C)(C)c1ccccc1C2(C)C ; Cc1cc2c(cc1N1c3cc4c(cc3B3c5ccc6sc7cc8c(cc7c6c5N(c5ccc(C(C)(C)C)cc5-c5ccccc5)c5cc(-c6c(C)cccc6C)cc1c53)C(C)(C)CCC8(C)C)C(C)(C)c1ccccc1C4(C)C)C(C)(C)c1ccccc1C2(C)C]

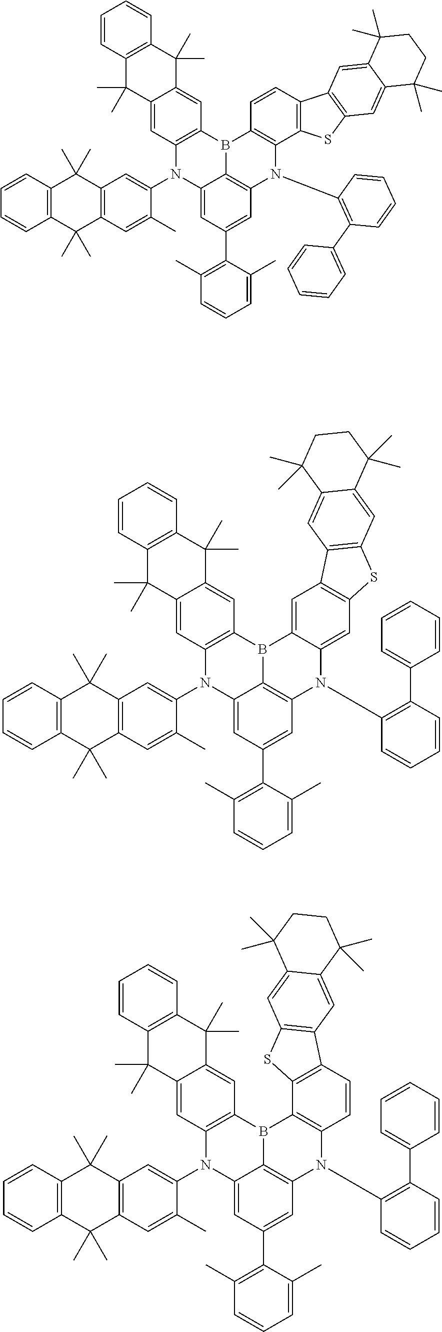 [SMILES: Cc1cc2c(cc1N1c3cc4c(cc3B3c5ccc6c(sc7cc8c(cc76)C(C)(C)CCC8(C)C)c5N(c5ccccc5-c5ccccc5)c5cc(-c6c(C)cccc6C)cc1c53)C(C)(C)c1ccccc1C4(C)C)C(C)(C)c1ccccc1C2(C)C ; Cc1cc2c(cc1N1c3cc4c(cc3B3c5cc6c(cc5N(c5ccccc5-c5ccccc5)c5cc(-c7c(C)cccc7C)cc1c53)sc1cc3c(cc16)C(C)(C)CCC3(C)C)C(C)(C)c1ccccc1C4(C)C)C(C)(C)c1ccccc1C2(C)C ; Cc1cc2c(cc1N1c3cc4c(cc3B3c5c1cc(-c1c(C)cccc1C)cc5N(c1ccccc1-c1ccccc1)c1ccc5c(sc6cc7c(cc65)C(C)(C)CCC7(C)C)c13)C(C)(C)c1ccccc1C4(C)C)C(C)(C)c1ccccc1C2(C)C]

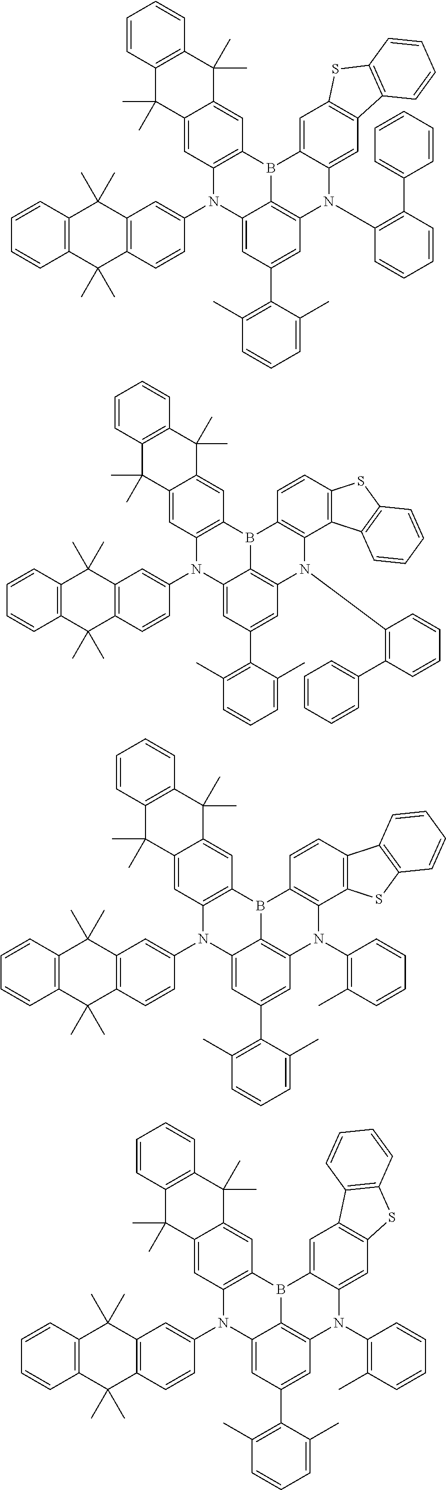

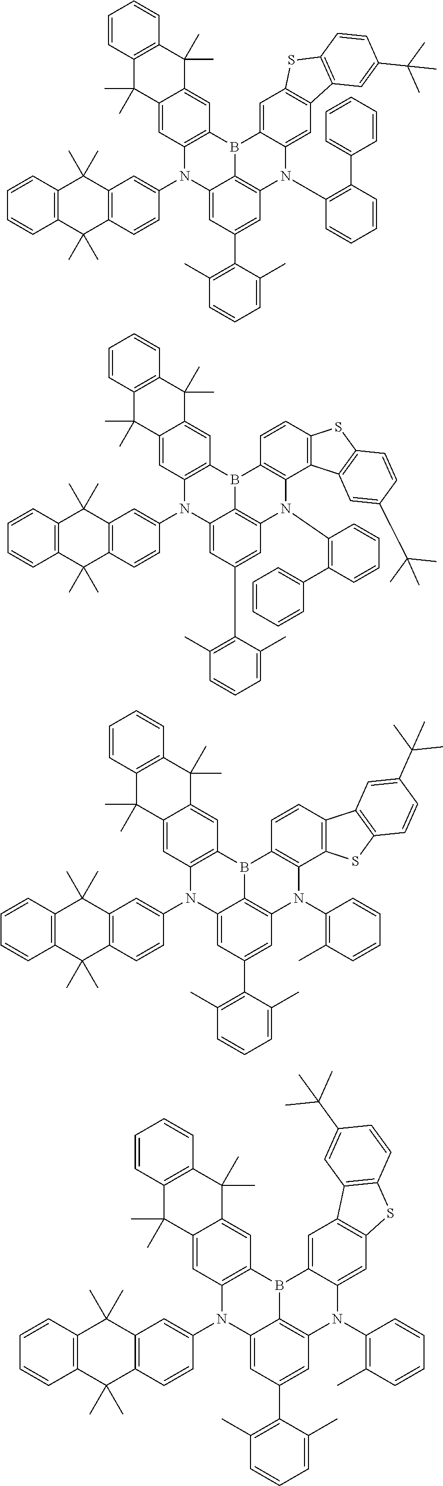

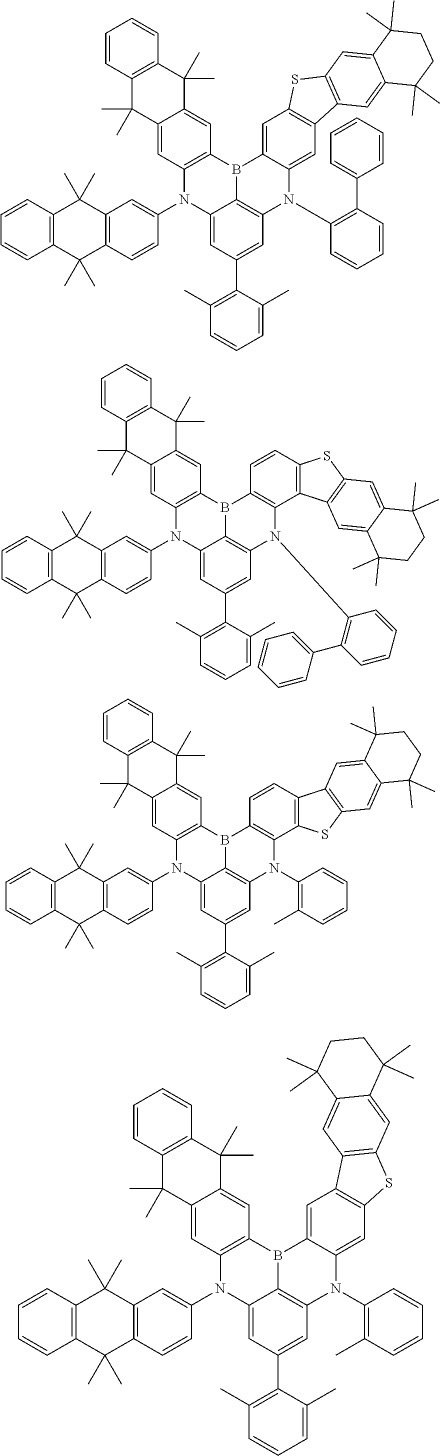

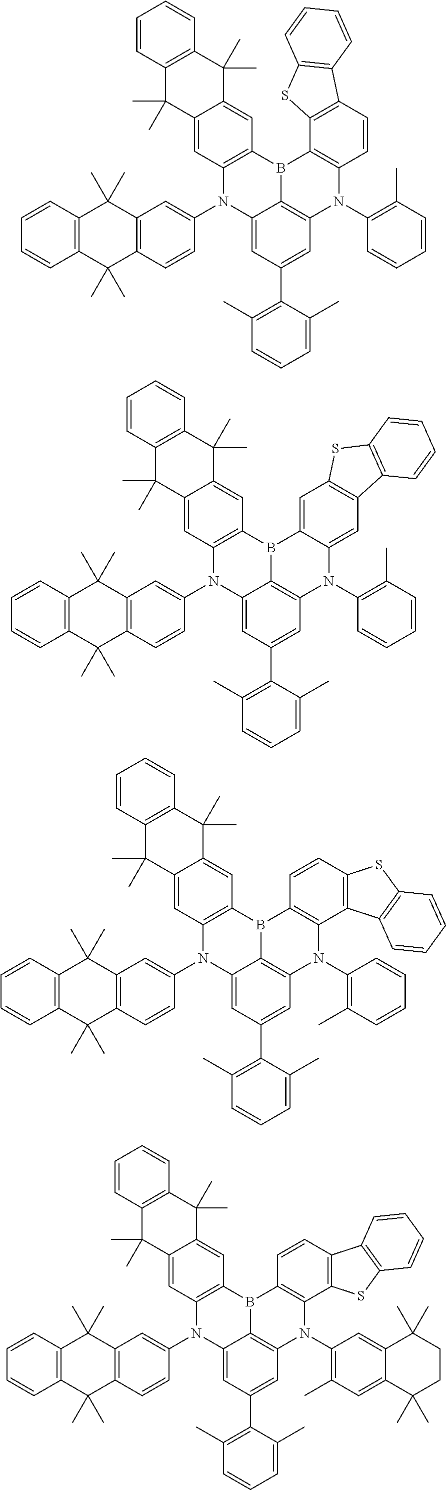

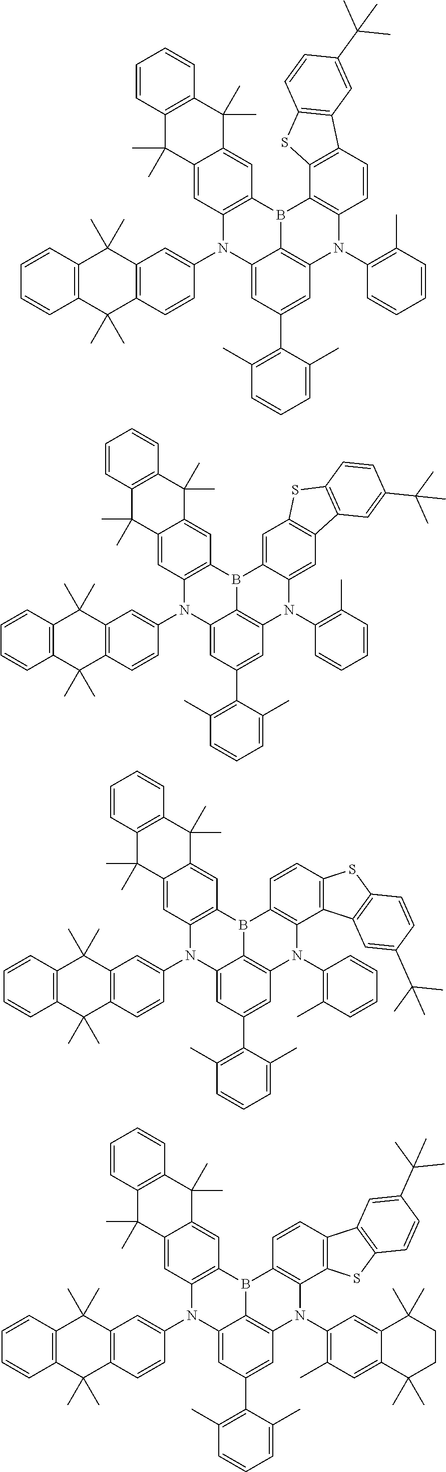

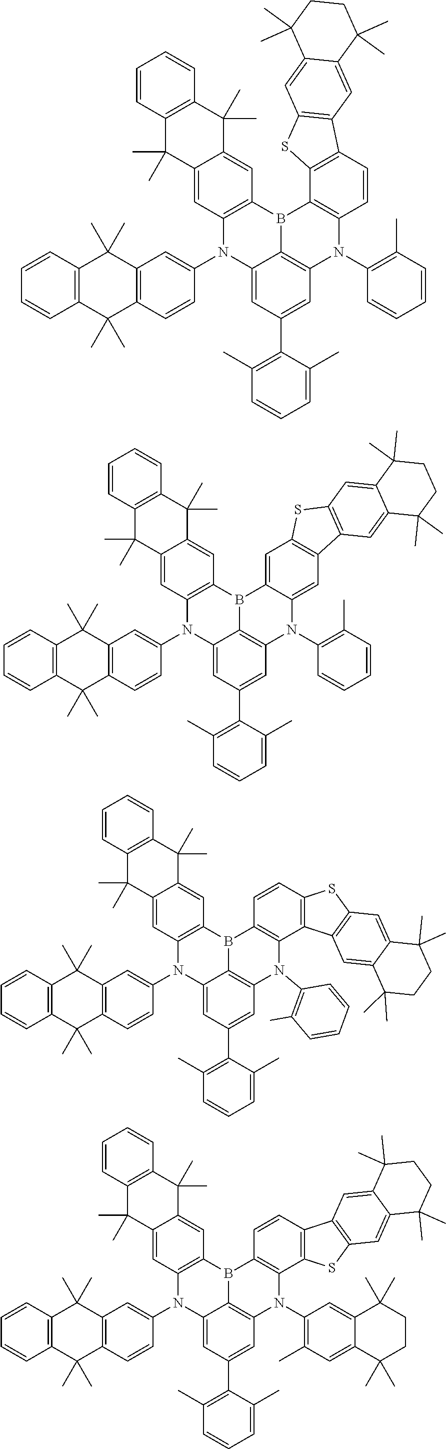

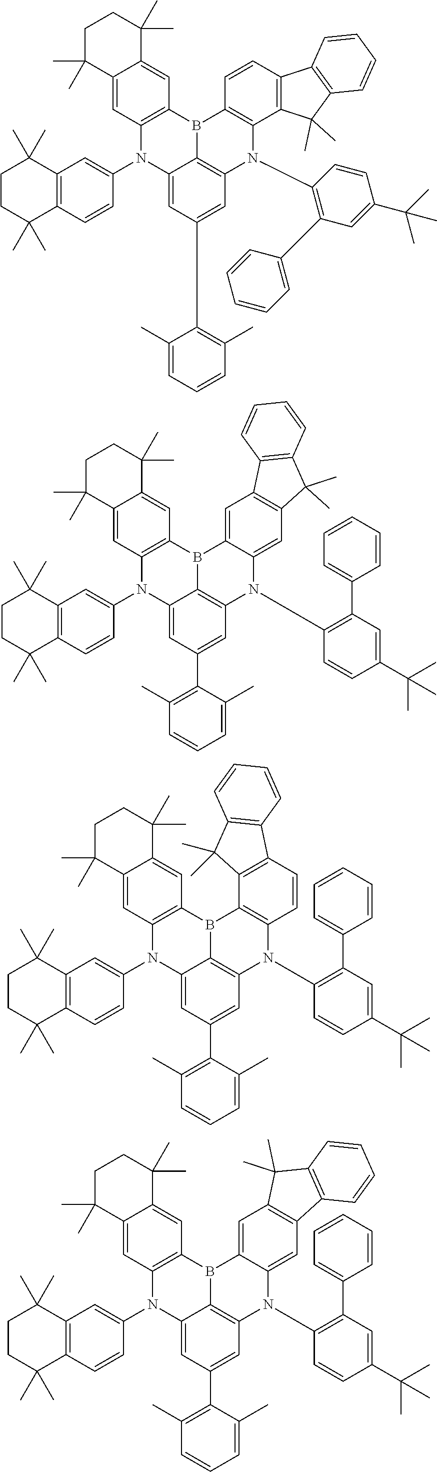

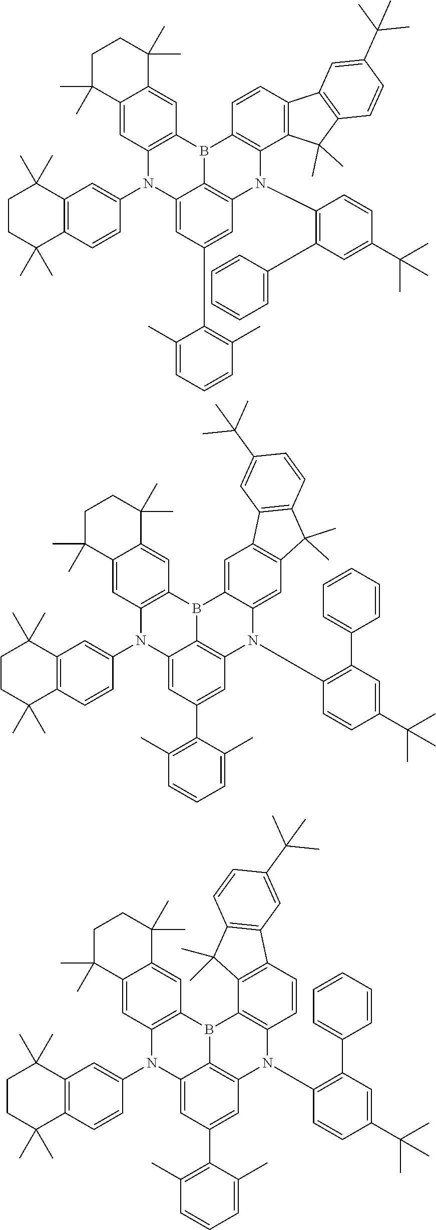

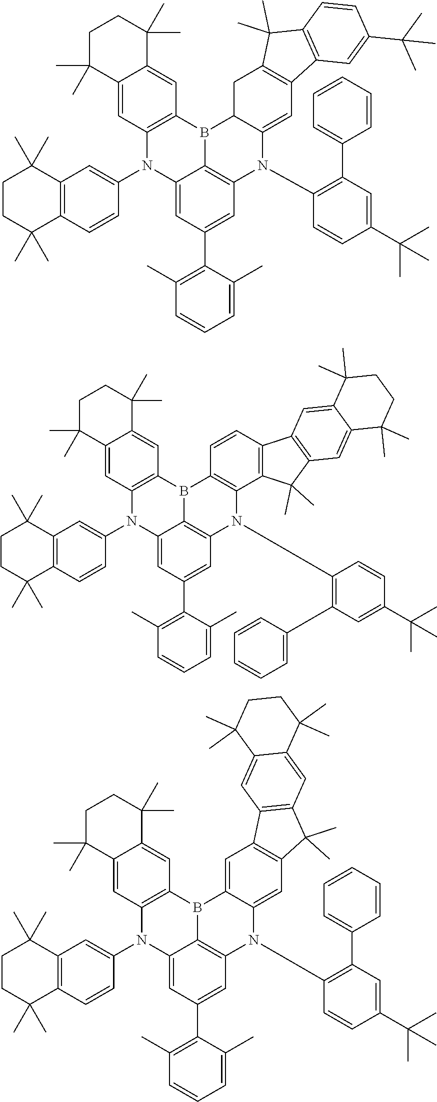

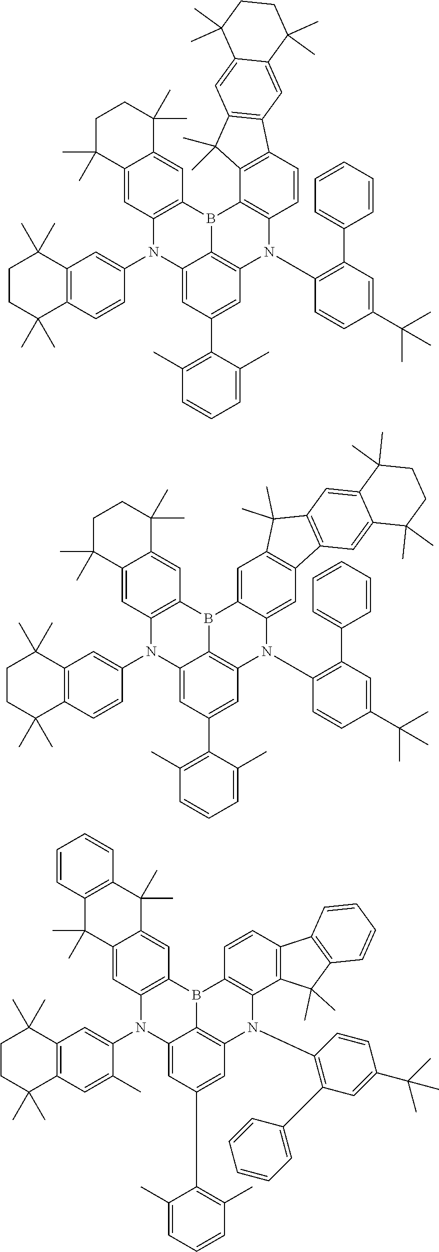 [SMILES: Cc1cccc(C)c1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1ccccc1-6)C(C)(C)c1ccccc1C4(C)C)C(C)(C)CCC2(C)C]

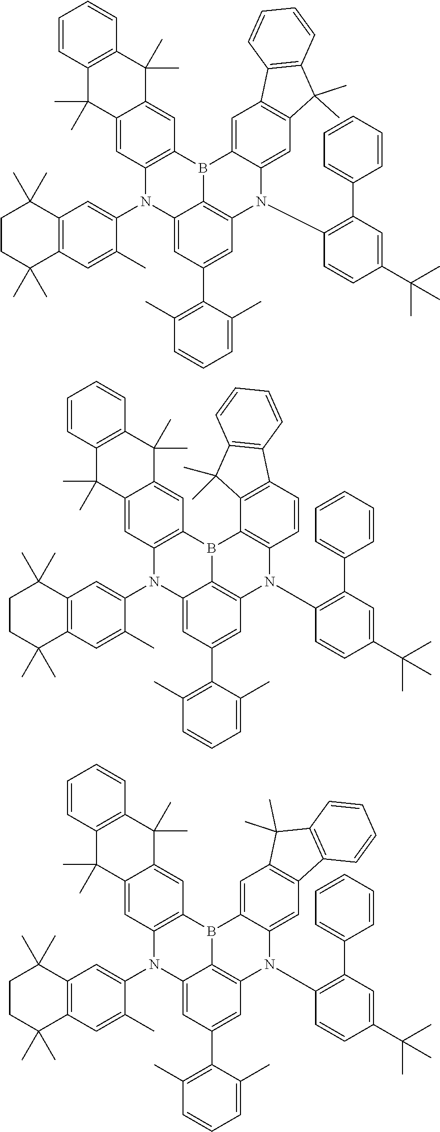

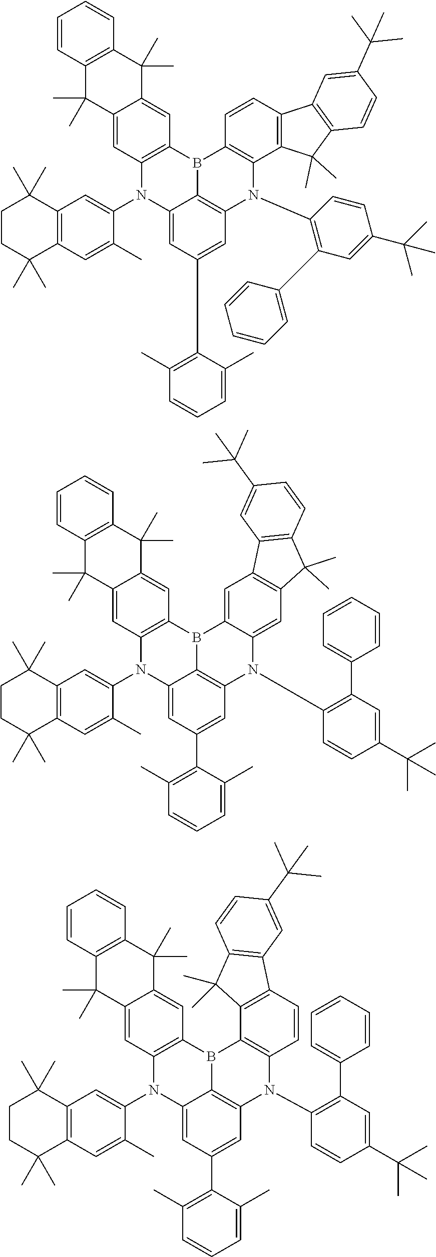

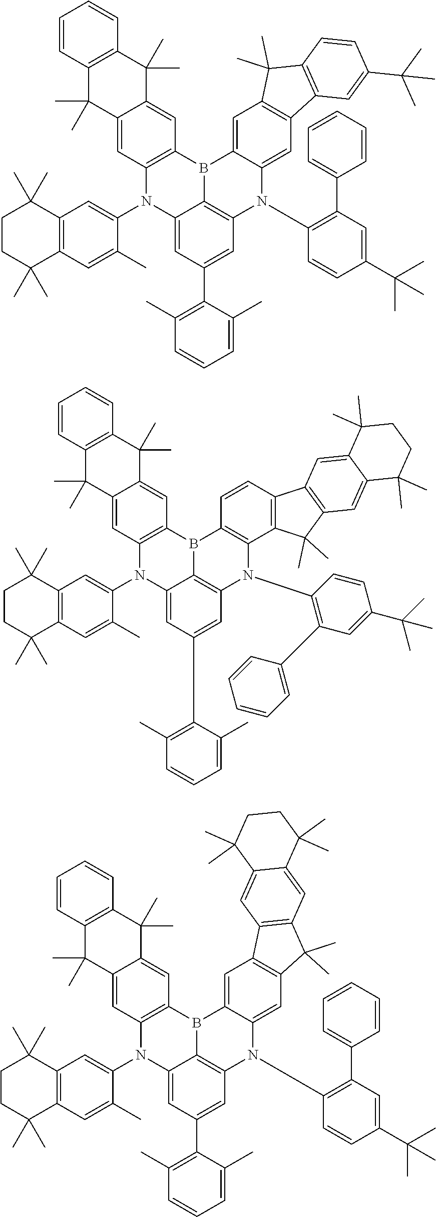 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C]

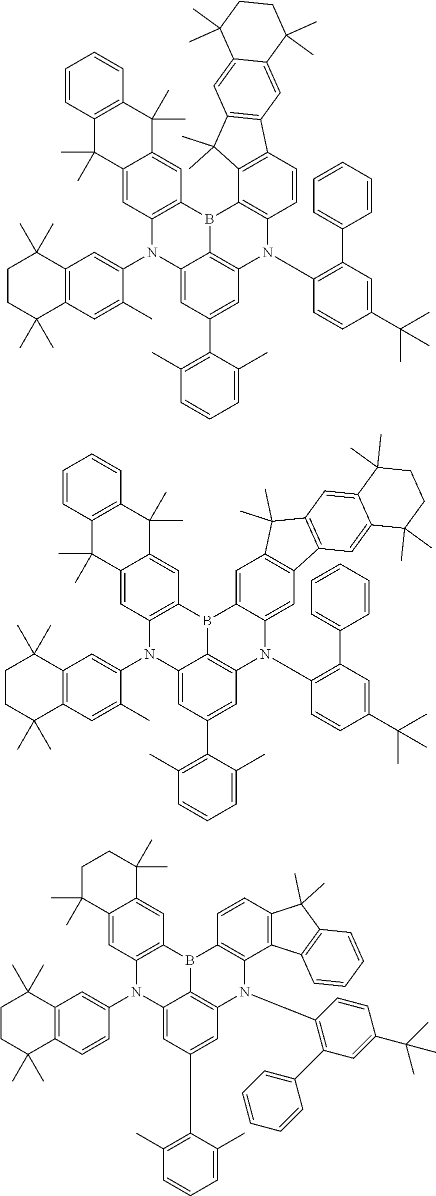

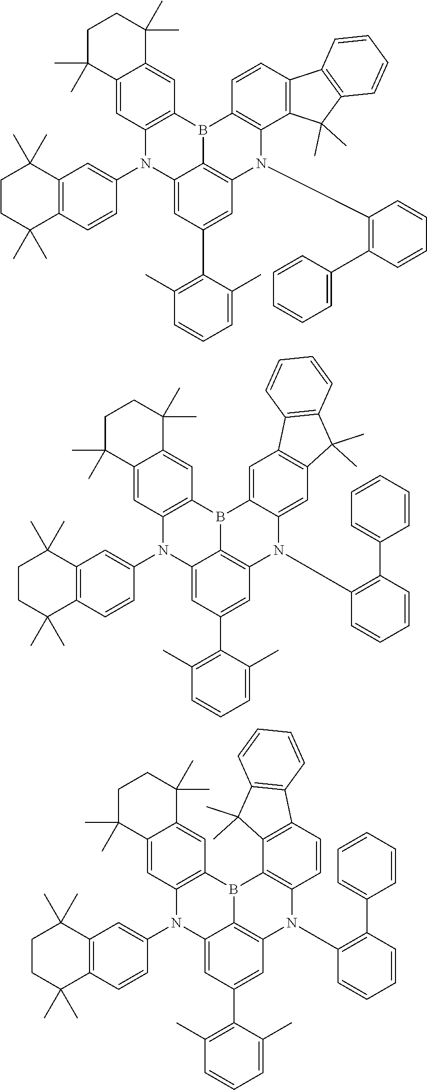

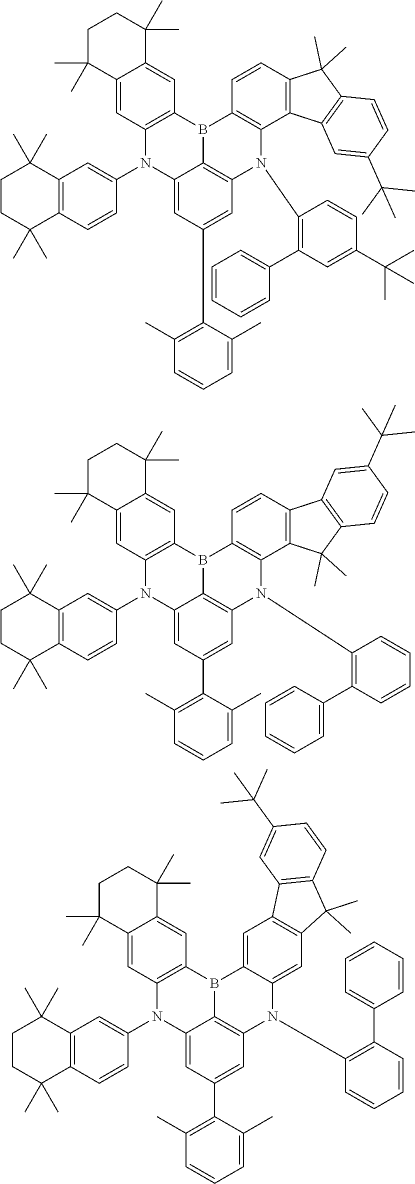

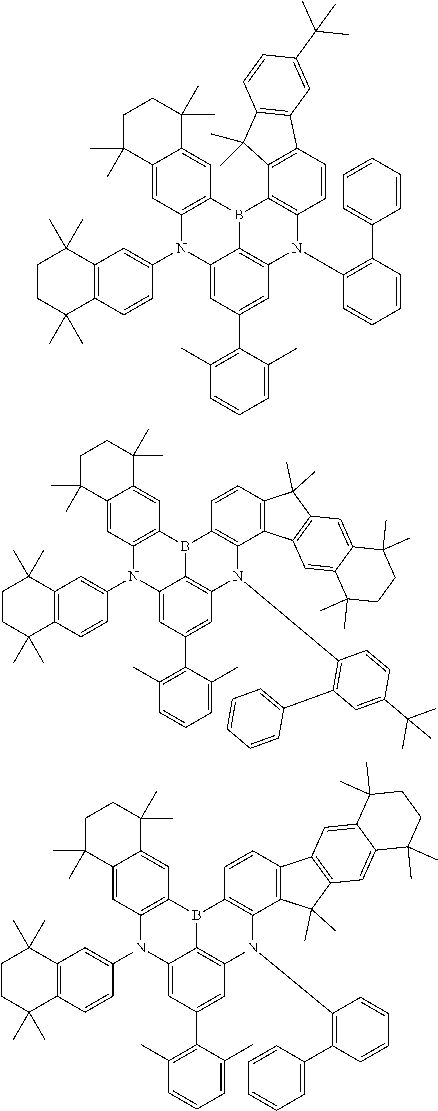

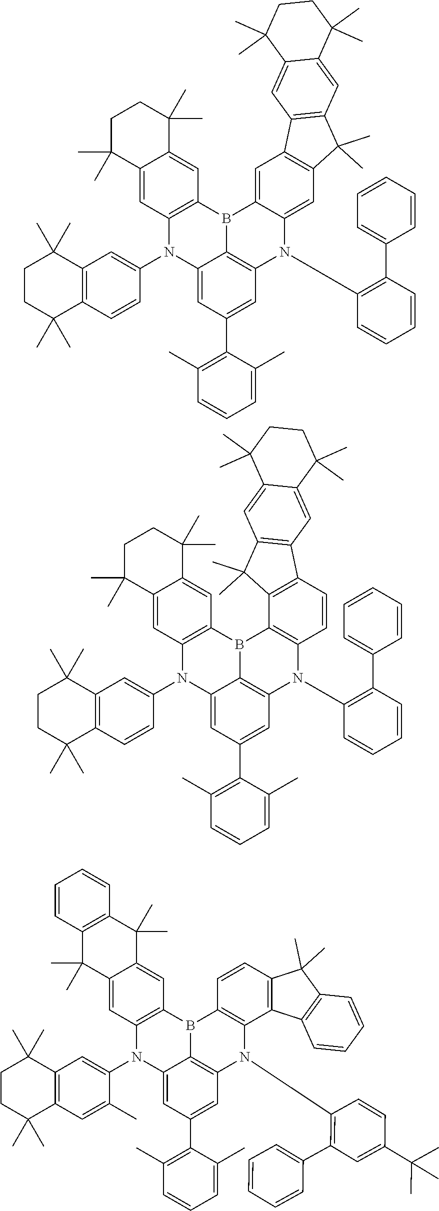

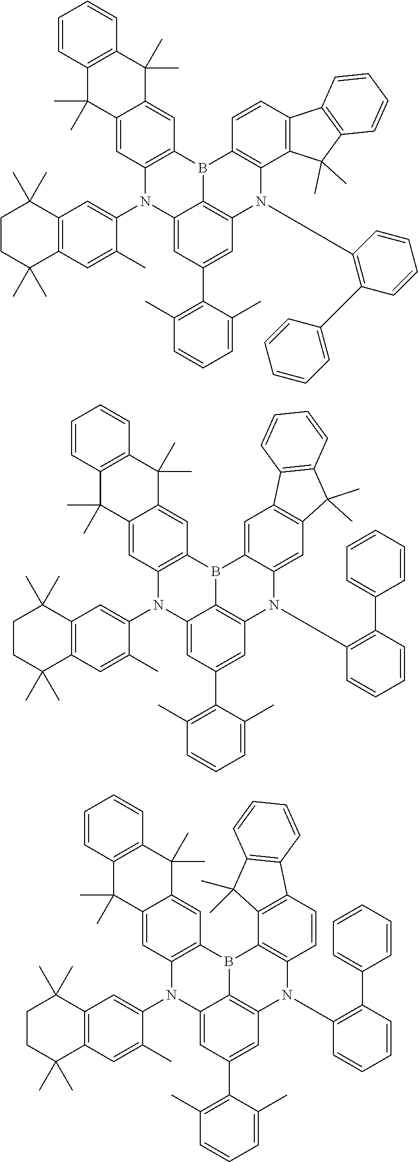

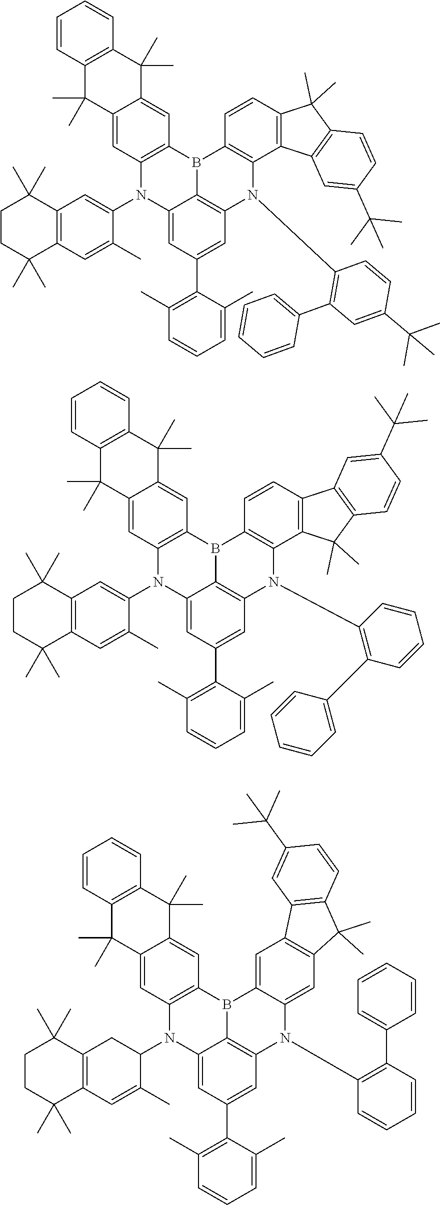

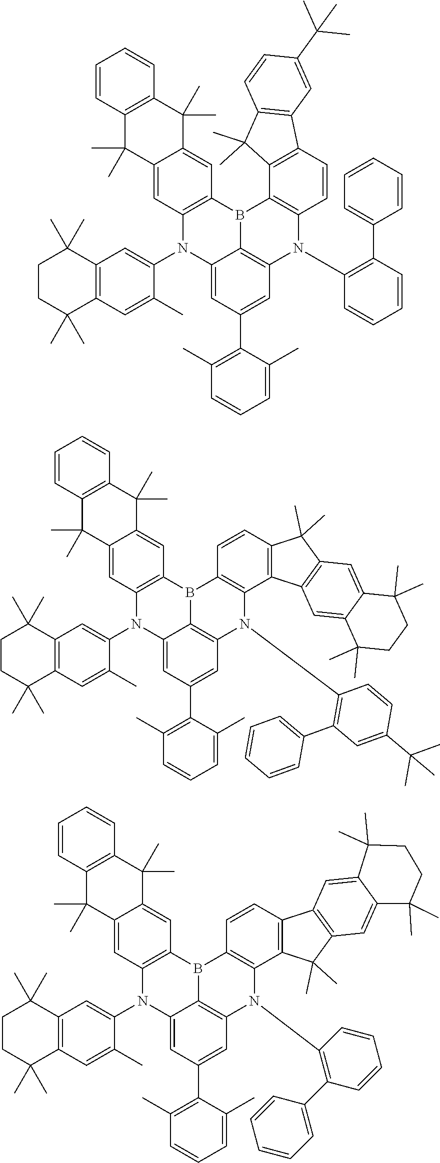 [SMILES: Cc1cc2c(cc1N1c3cc4c(cc3B3c5c1cc(-c1c(C)cccc1C)cc5N(c1ccccc1-c1ccccc1)c1ccc5c(c13)C(C)(C)c1ccc(C(C)(C)C)cc1-5)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C]

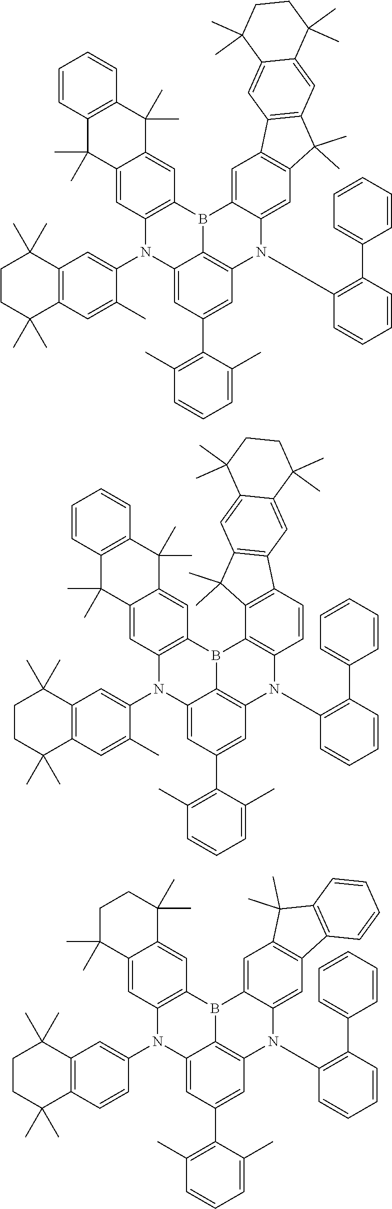

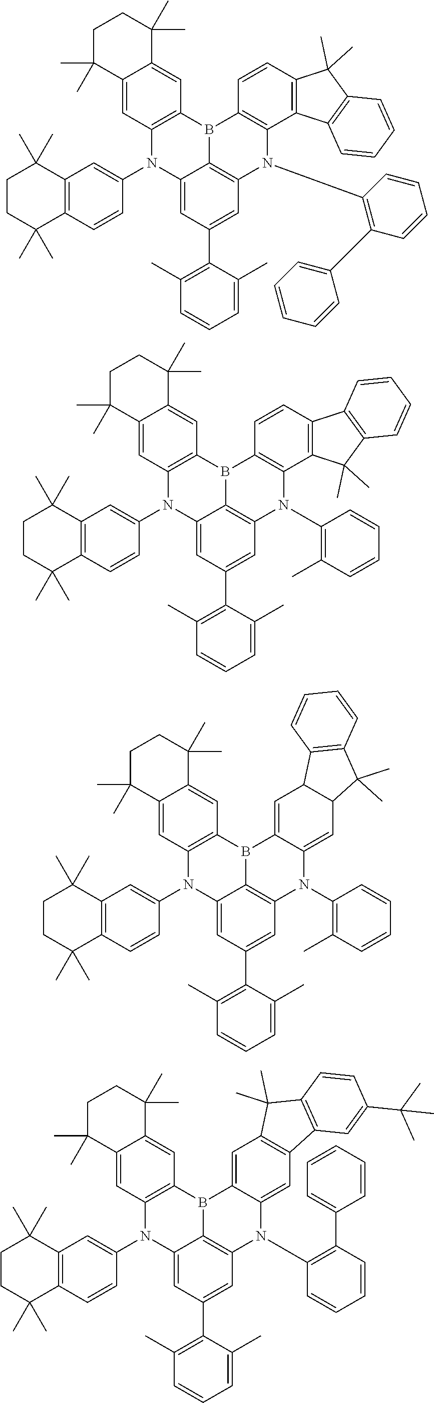

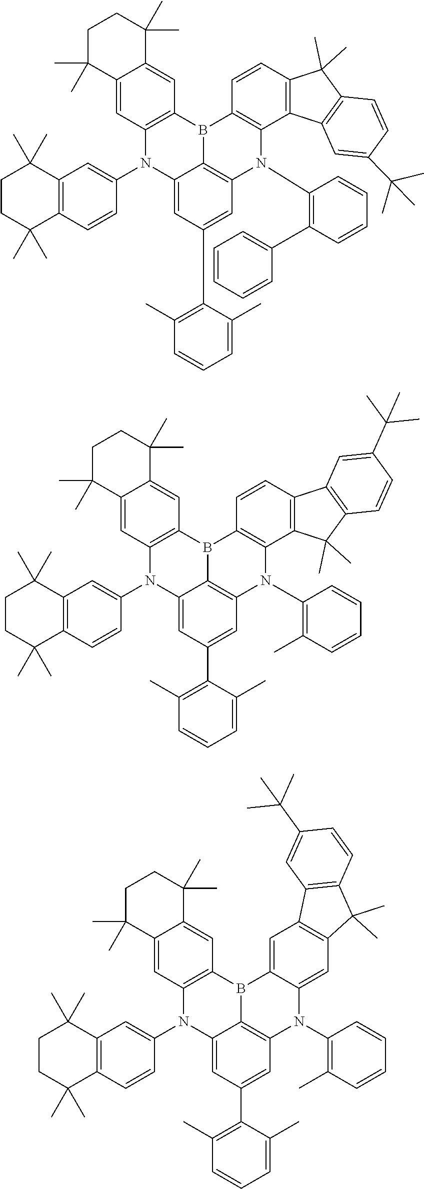 [SMILES: Cc1cccc(C)c1-c1cc2c3c(c1)N(c1ccccc1-c1ccccc1)c1c(ccc4c1-c1cc(C(C)(C)C)ccc1C4(C)C)B3c1cc3c(cc1N2c1ccc2c(c1)C(C)(C)CCC2(C)C)C(C)(C)CCC3(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(c21)C(C)(C)c1ccc(C(C)(C)C)cc1-3 ; Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)-c1cc(C(C)(C)C)ccc1C3(C)C]

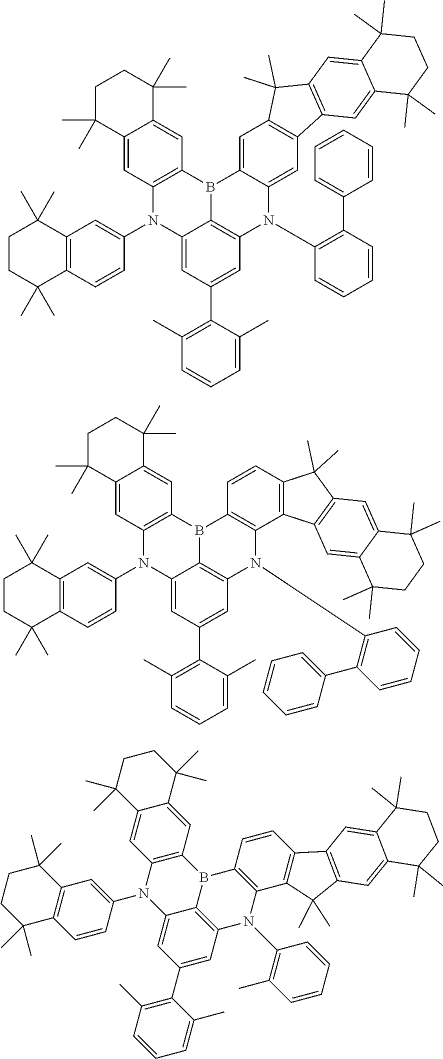

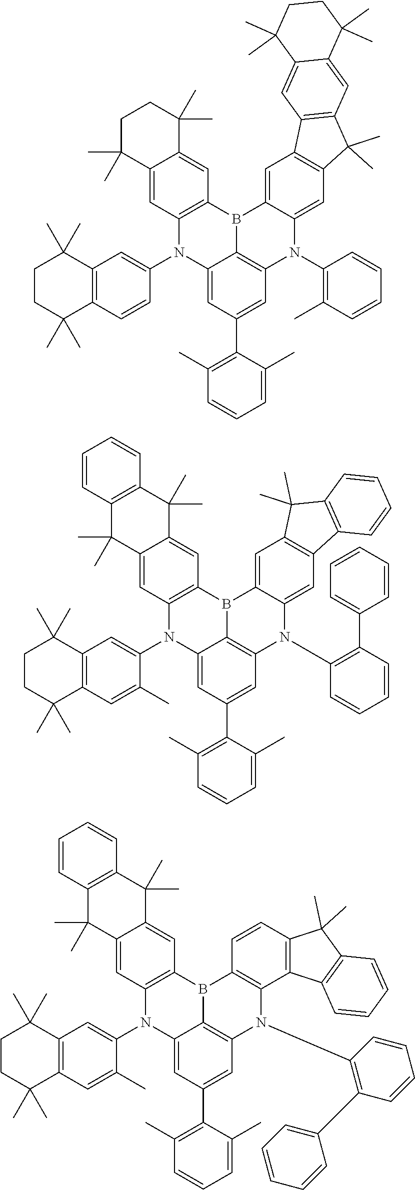 [SMILES: Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)-c1cc2c(cc1C3(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)-c1ccccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)-c1ccccc1C6(C)C)C(C)(C)c1ccccc1C4(C)C)C(C)(C)CCC2(C)C]

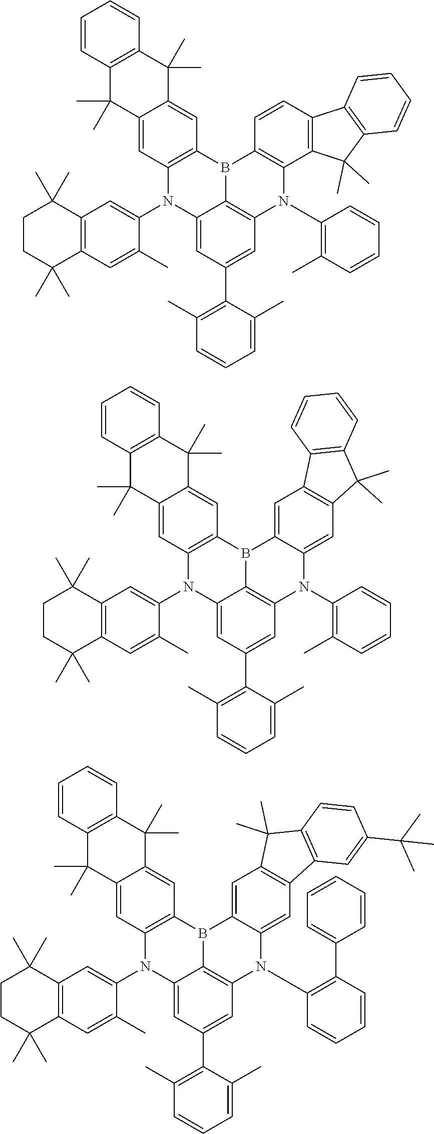 [SMILES: Cc1cc2c(cc1N1c3cc4c(cc3B3c5ccc6c(c5N(c5ccccc5C)c5cc(-c7c(C)cccc7C)cc1c53)C(C)(C)c1ccccc1-6)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)-c1ccccc1C3(C)C ; Cc1cc2c(cc1N1c3cc4c(cc3B3c5cc6c(cc5N(c5ccccc5-c5ccccc5)c5cc(-c7c(C)cccc7C)cc1c53)-c1cc(C(C)(C)C)ccc1C6(C)C)C(C)(C)c1ccccc1C4(C)C)C(C)(C)CCC2(C)C]

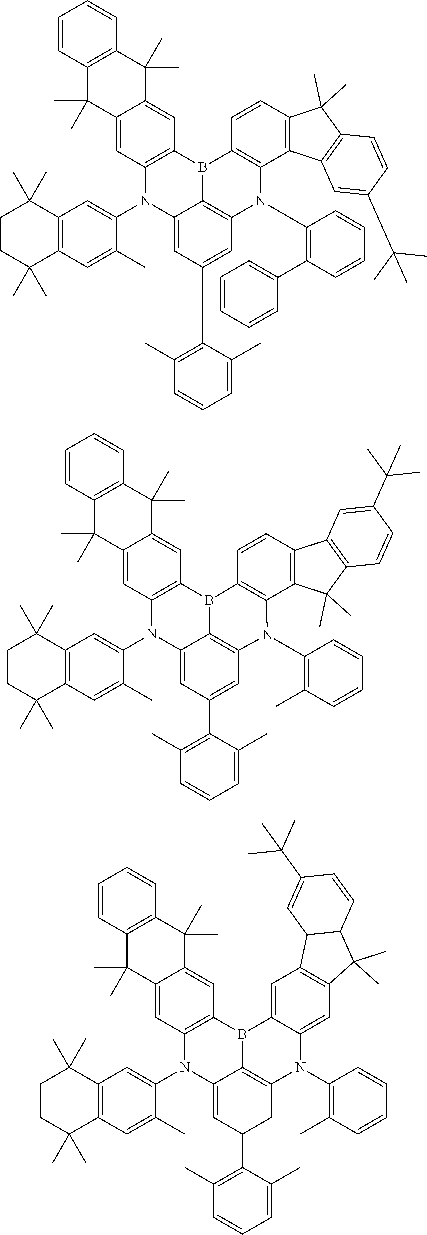

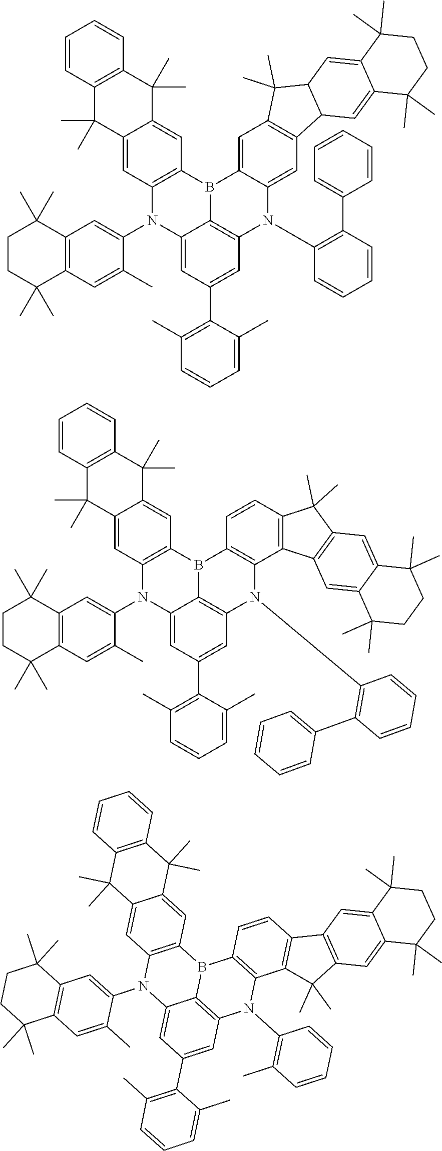 [SMILES: Cc1cc2c(cc1N1c3cc4c(cc3B3c5cc6c(cc5N(c5ccccc5-c5ccccc5)c5cc(-c7c(C)cccc7C)cc1c53)C1C=C3C(=CC1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5C)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C]

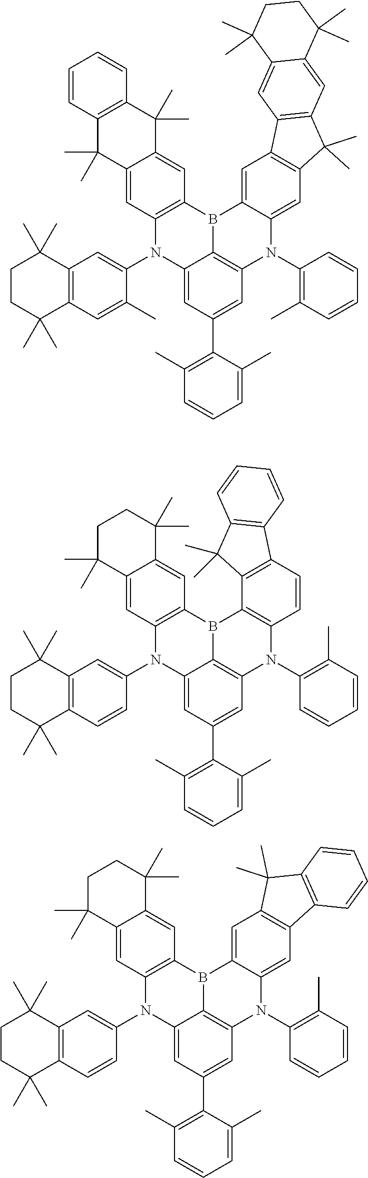

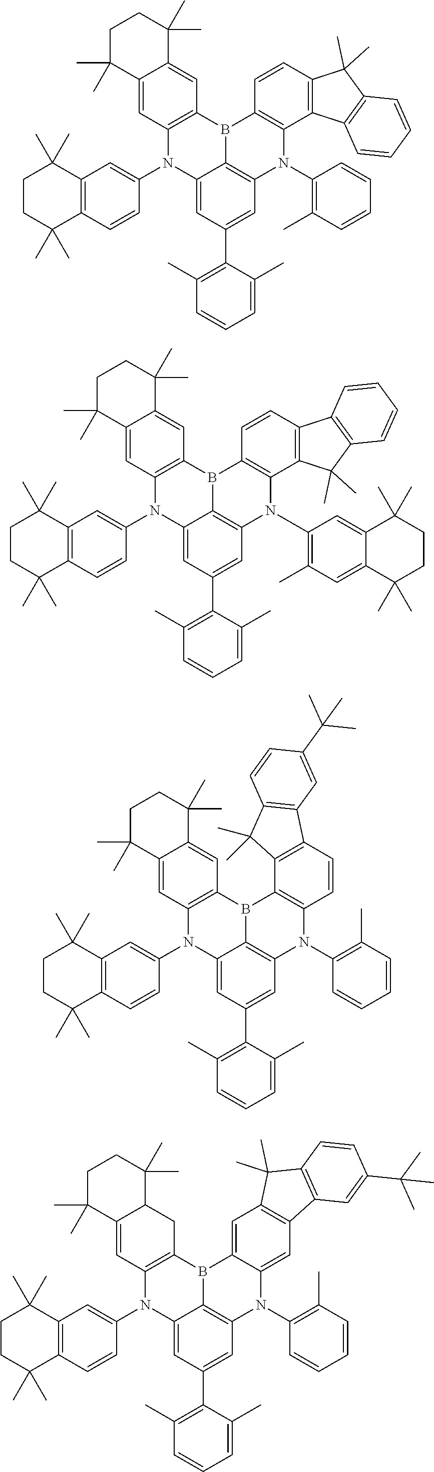

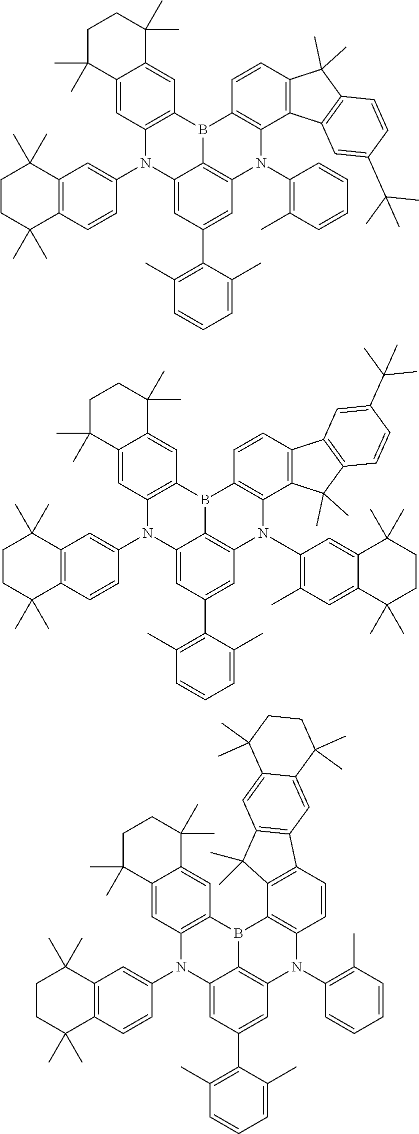

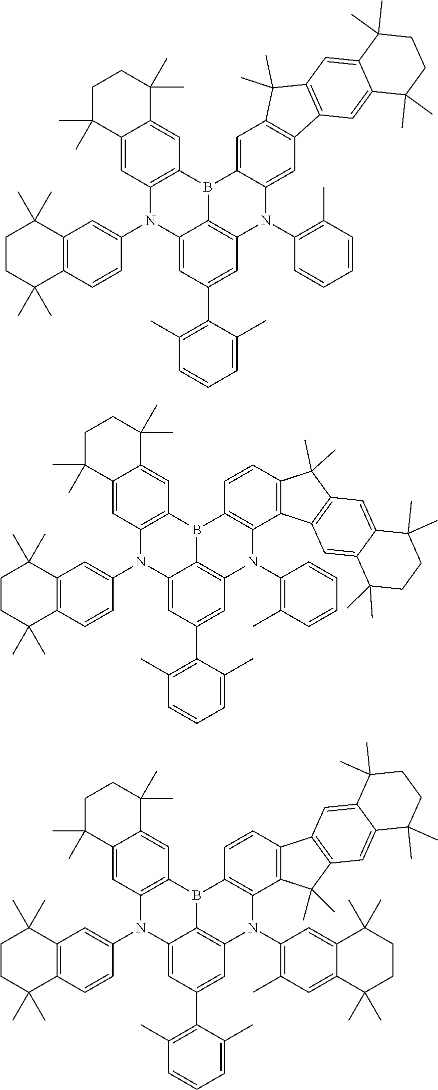

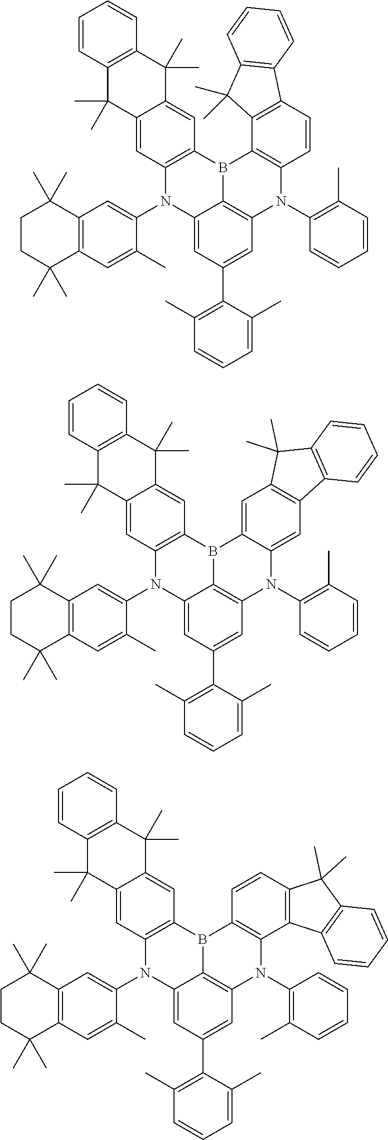 [SMILES: Cc1cc2c(cc1N1c3cc4c(cc3B3c5c1cc(-c1c(C)cccc1C)cc5N(c1ccccc1C)c1ccc5c(c13)C(C)(C)c1ccccc1-5)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)C(C)(C)c1ccccc1-3 ; Cc1cc2c(cc1N1c3cc4c(cc3B3c5ccc6c(c5N(c5ccccc5C)c5cc(-c7c(C)cccc7C)cc1c53)-c1ccccc1C6(C)C)C(C)(C)c1ccccc1C4(C)C)C(C)(C)CCC2(C)C]

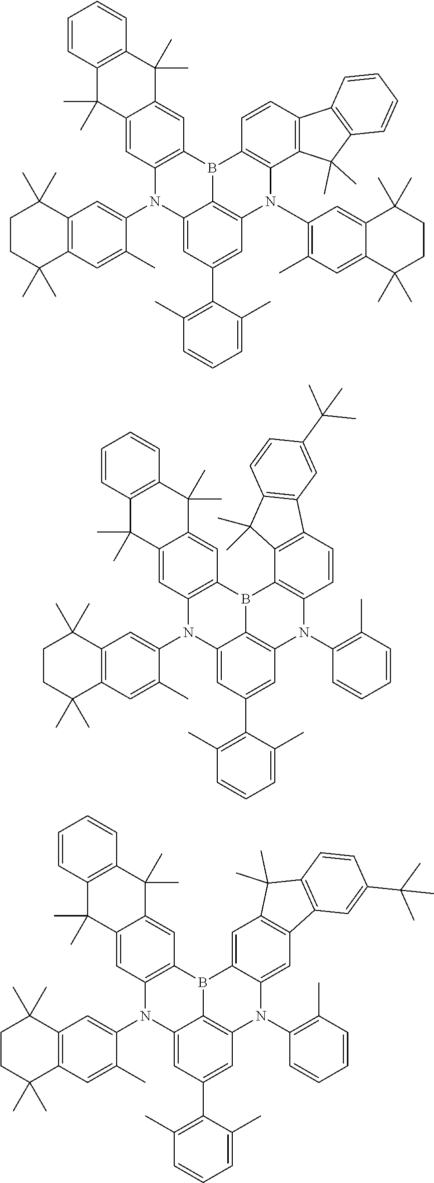 [SMILES: Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)C(C)(C)c1ccccc1-6)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(c13)C(C)(C)c1ccc(C(C)(C)C)cc1-5)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)C(C)(C)c1ccc(C(C)(C)C)cc1-3]

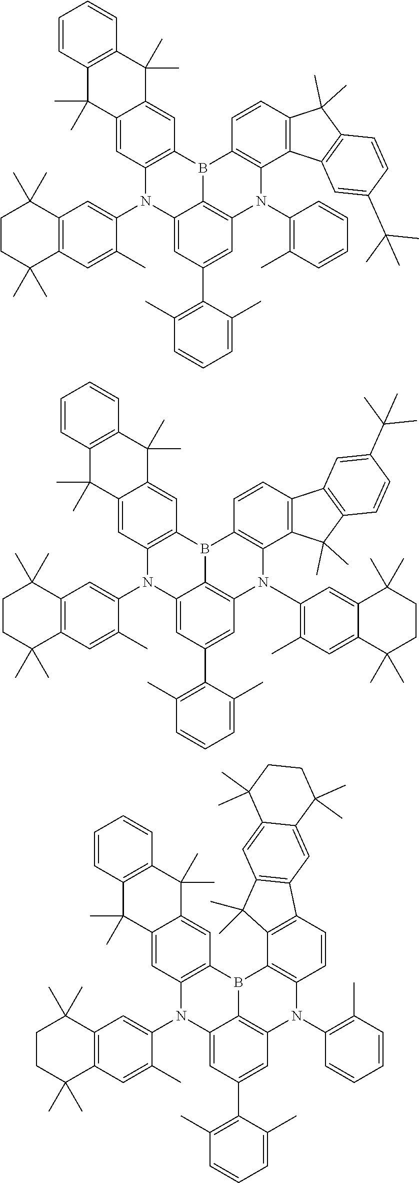

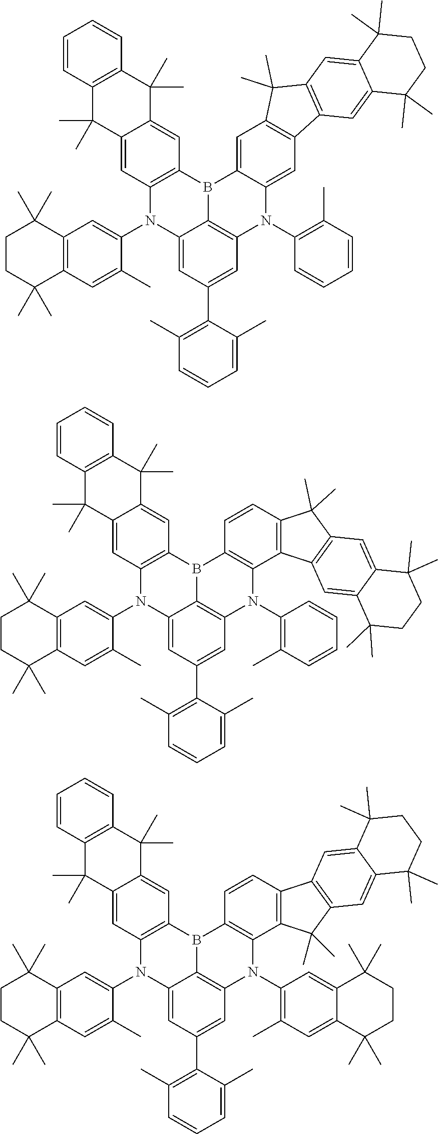 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)C(C)(C)c1cc2c(cc1-3)C(C)(C)CCC2(C)C ; Cc1cc2c(cc1N1c3cc4c(cc3B3c5ccc6c(c5N(c5ccccc5C)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C]

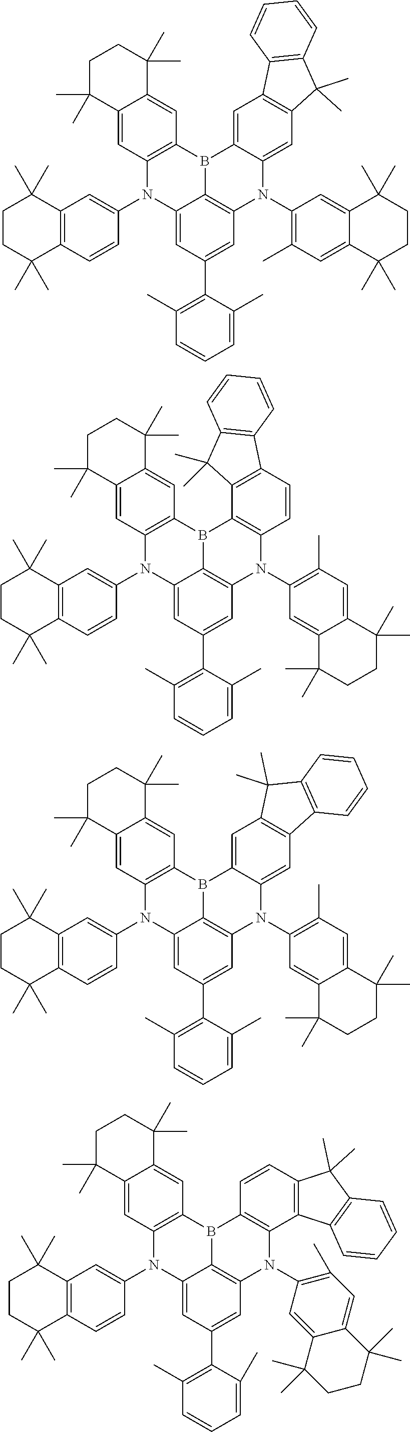

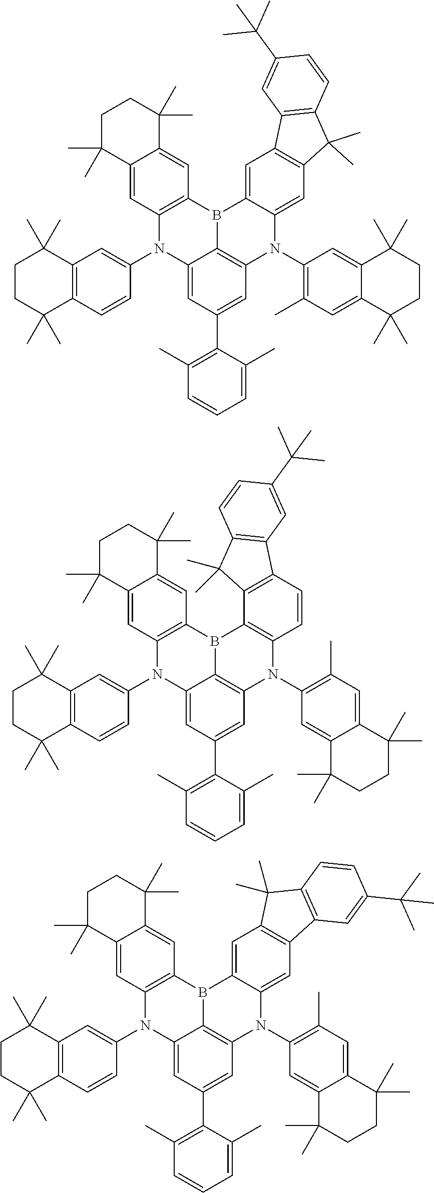

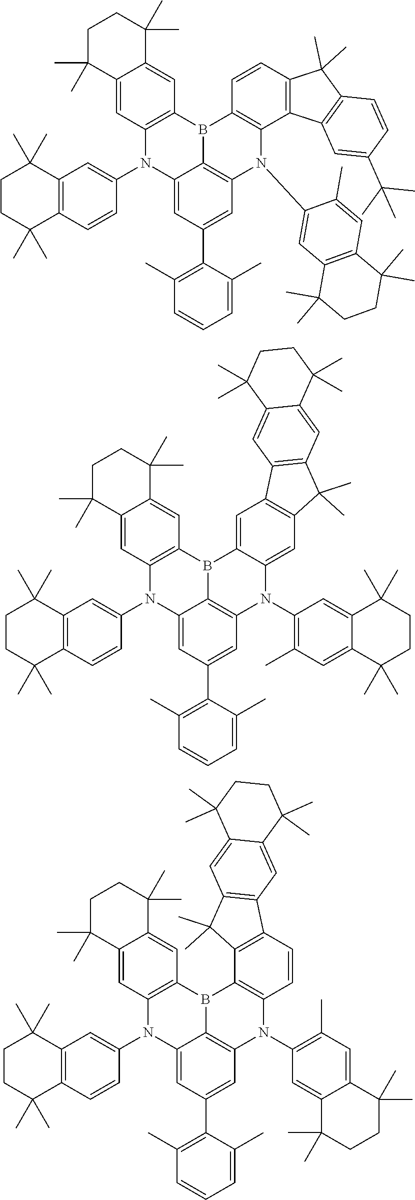

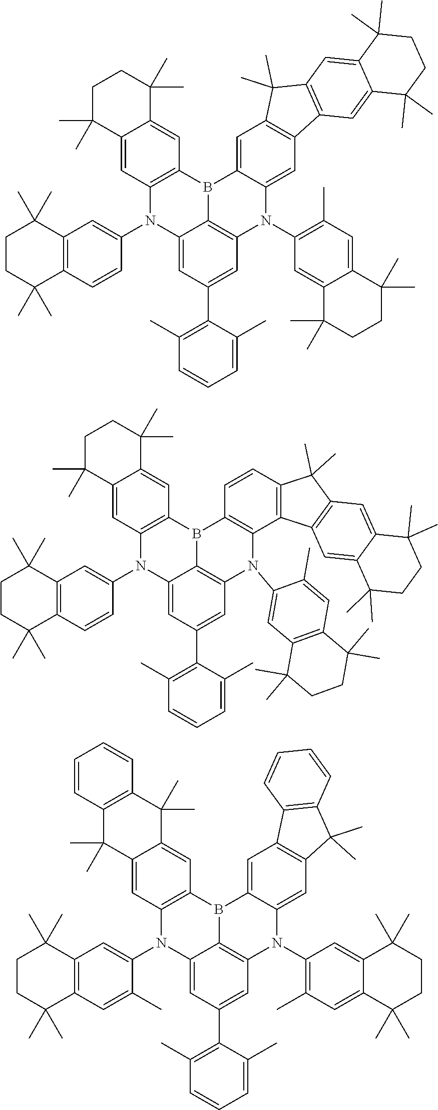

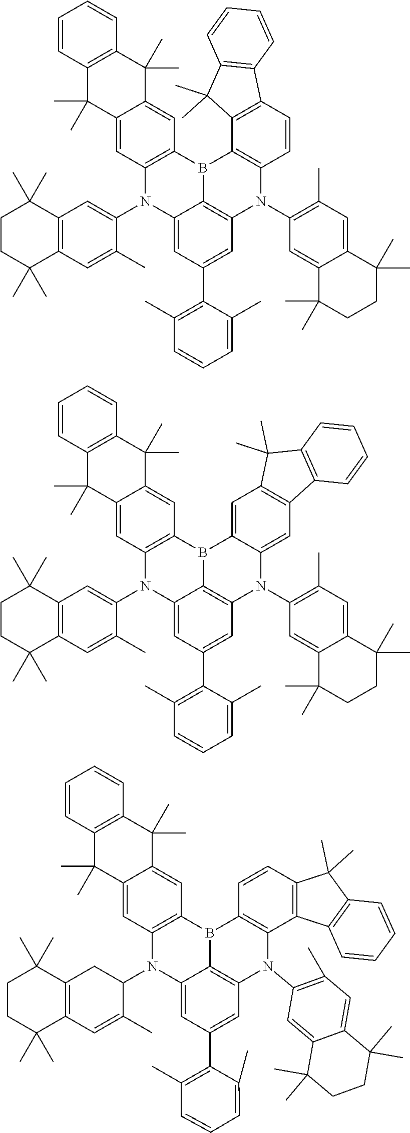 [SMILES: Cc1cc2c(cc1N1c3cc4c(cc3B3c5c1cc(-c1c(C)cccc1C)cc5N(c1cc5c(cc1C)C(C)(C)CCC5(C)C)c1ccc5c(c13)C(C)(C)c1ccccc1-5)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)C(C)(C)c1ccccc1-4)C(C)(C)CCC2(C)C ; CC1=CC2=C(CC1N1c3cc4c(cc3B3c5ccc6c(c5N(c5cc7c(cc5C)C(C)(C)CCC7(C)C)c5cc(-c7c(C)cccc7C)cc1c53)-c1ccccc1C6(C)C)C(C)(C)c1ccccc1C4(C)C)C(C)(C)CCC2(C)C]

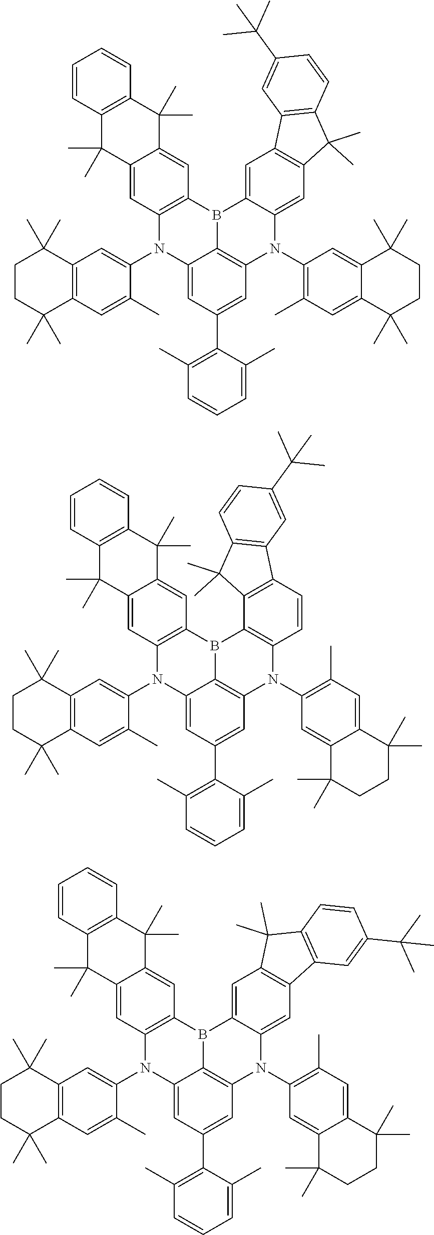

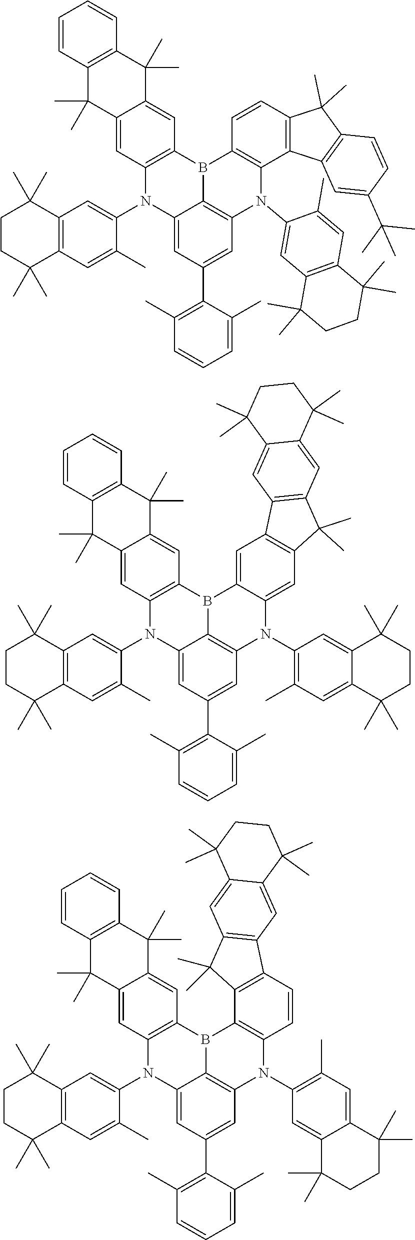

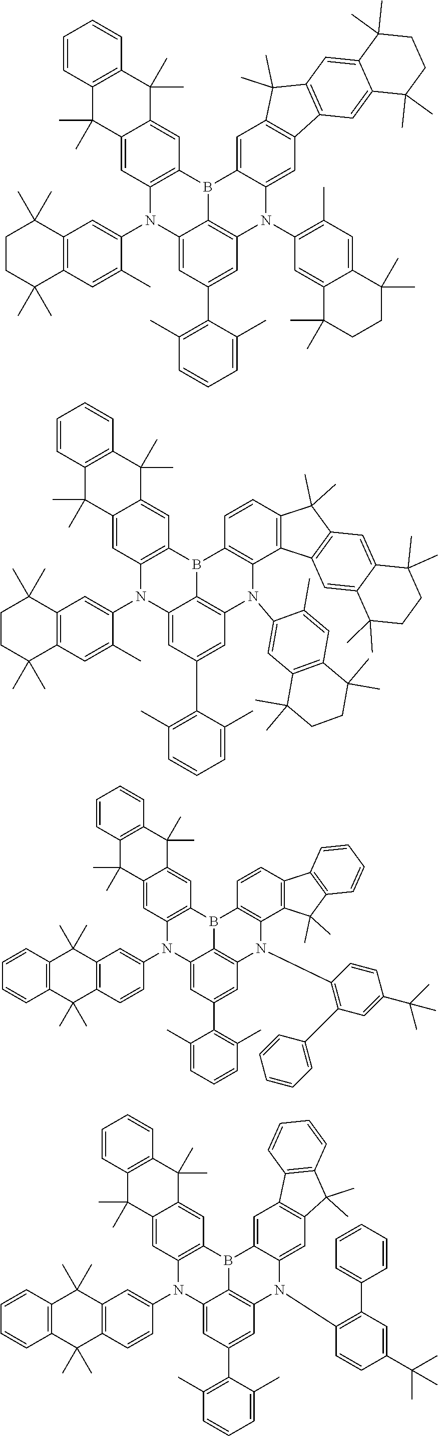

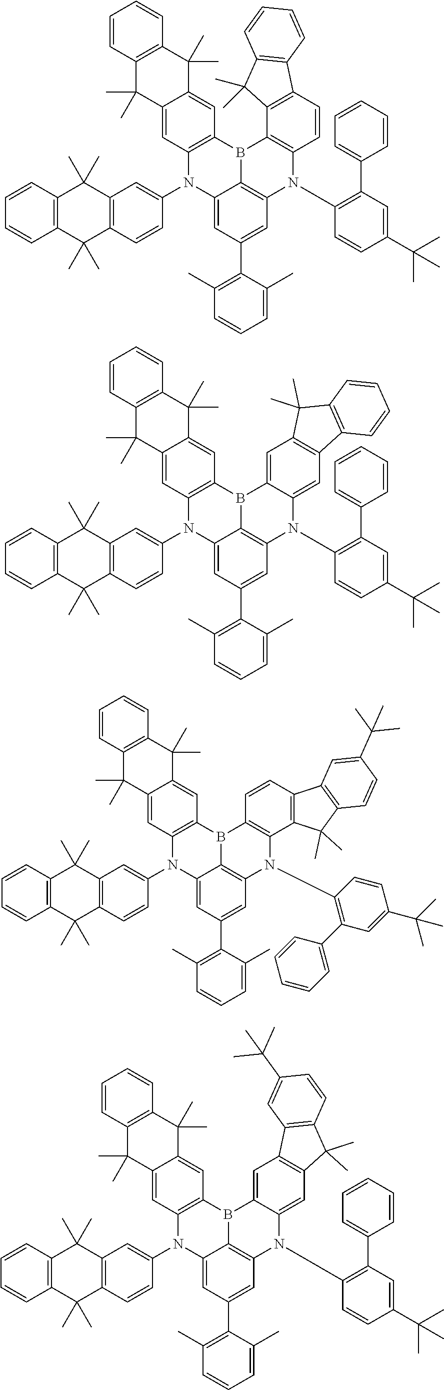

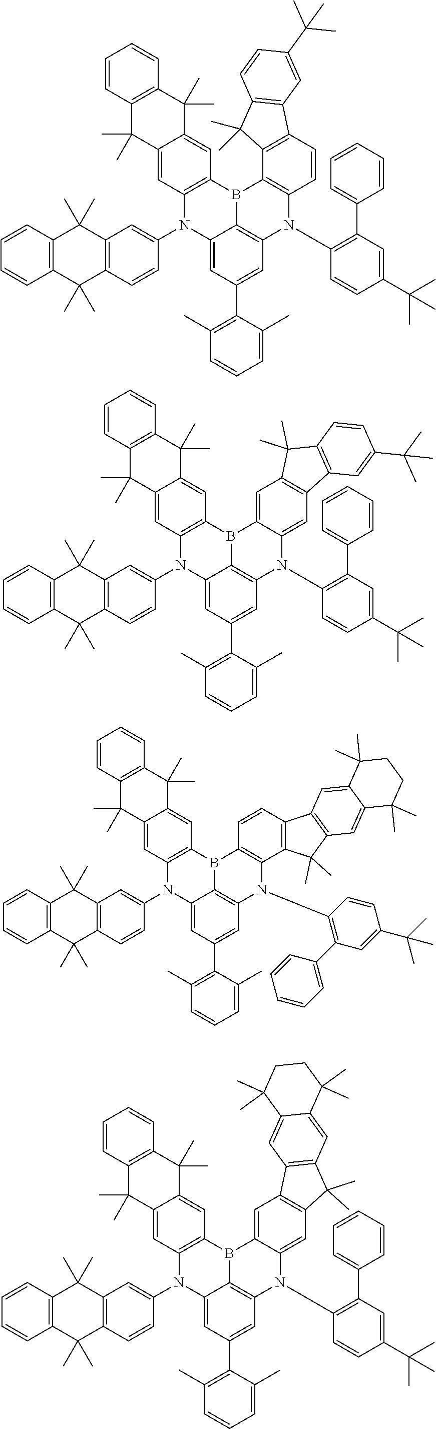

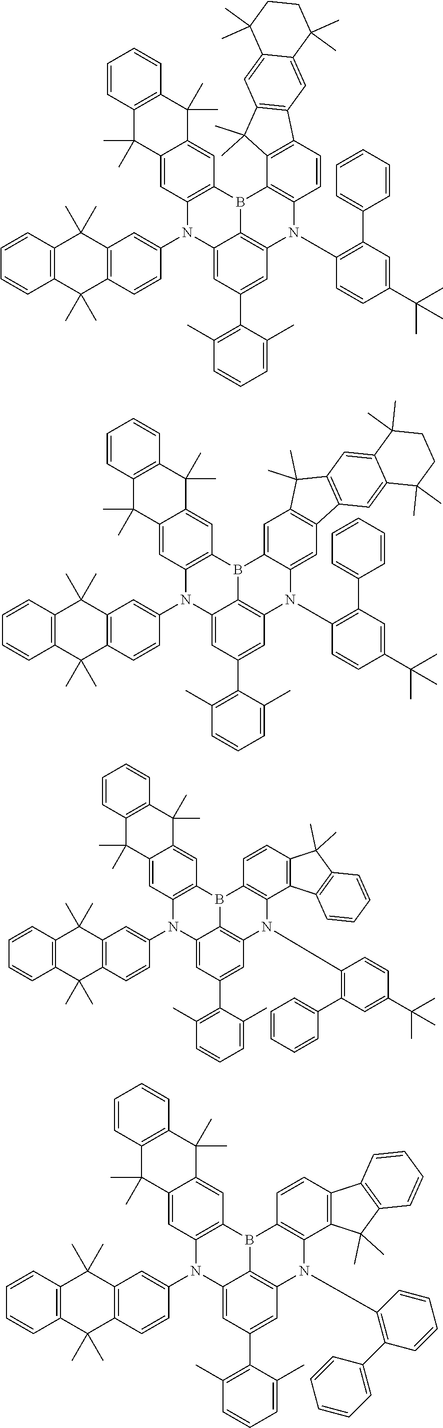

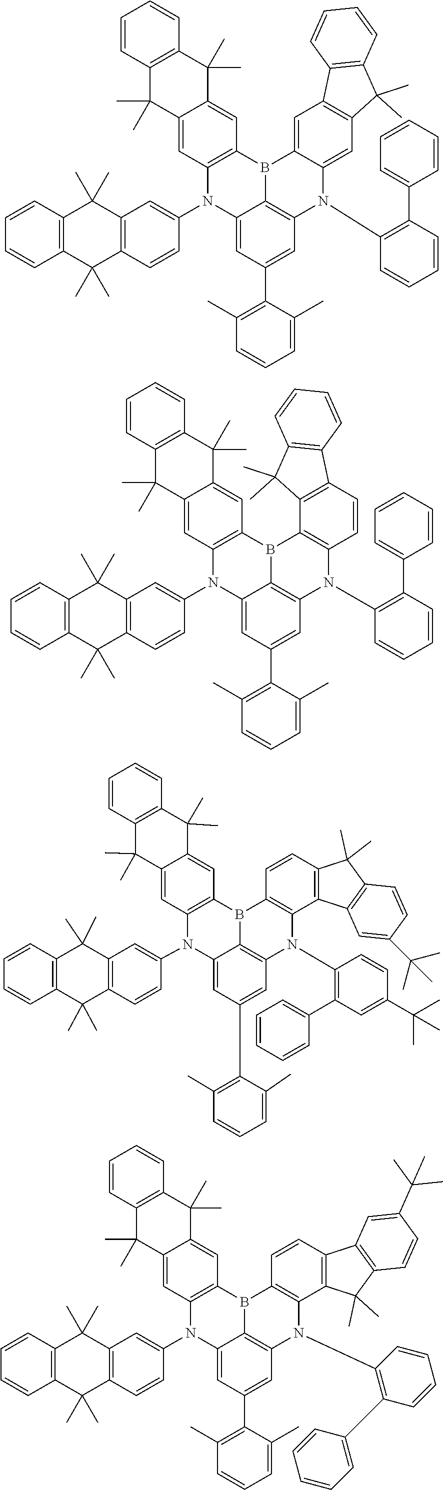

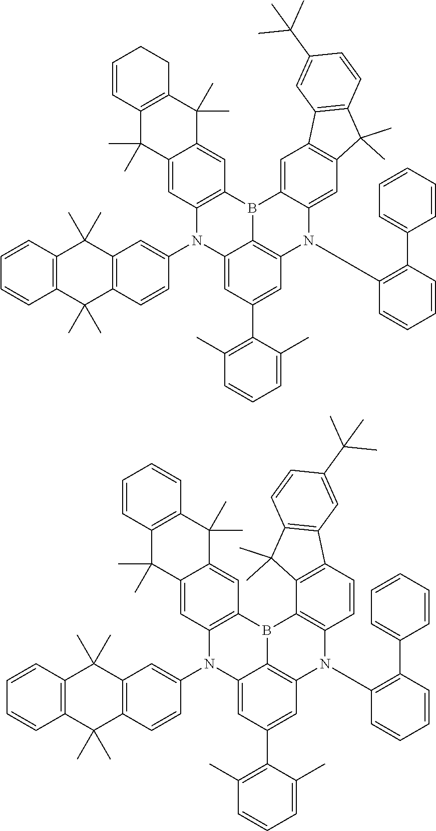 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)C1=C(CCC=C1)C3(C)C)-c1cc(C(C)(C)C)ccc1C4(C)C ; Cc1cccc(C)c1-c1cc2c3c(c1)N(c1ccccc1-c1ccccc1)c1ccc4c(c1B3c1cc3c(cc1N2c1ccc2c(c1)C(C)(C)c1ccccc1C2(C)C)C(C)(C)c1ccccc1C3(C)C)C(C)(C)c1ccc(C(C)(C)C)cc1-4]

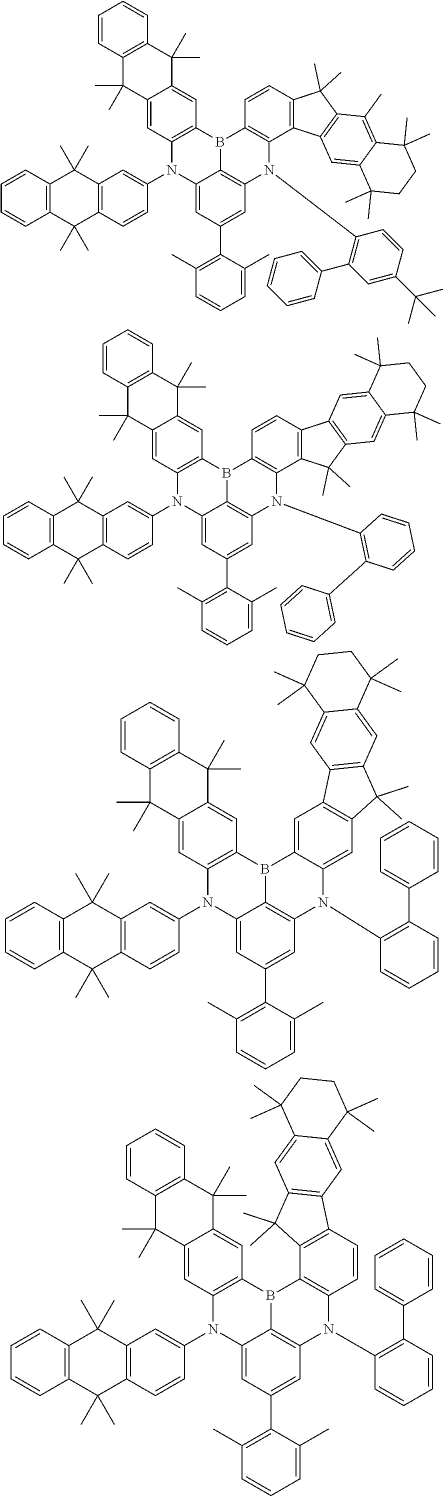

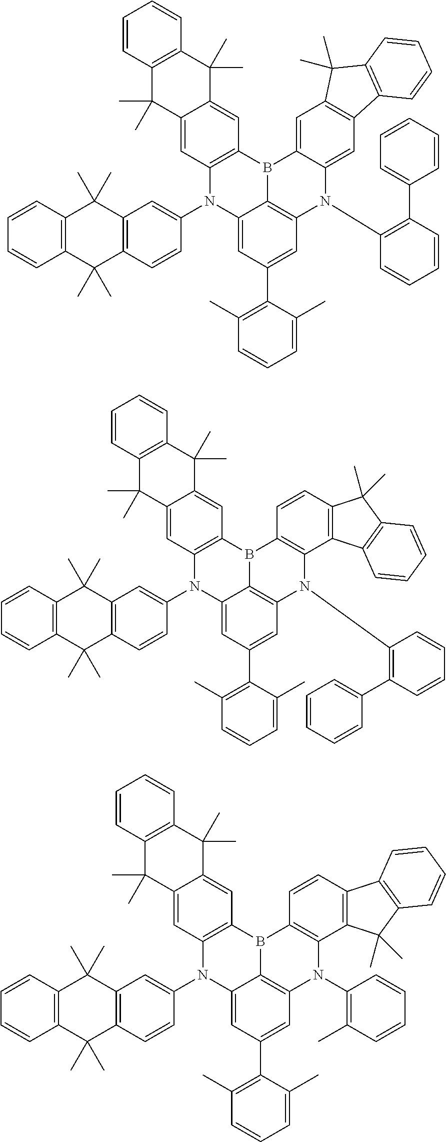 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1-4 ; Cc1cccc(C)c1-c1cc2c3c(c1)N(c1ccccc1-c1ccccc1)c1c(ccc4c1-c1ccccc1C4(C)C)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)C(C)(C)c1ccccc1-3]

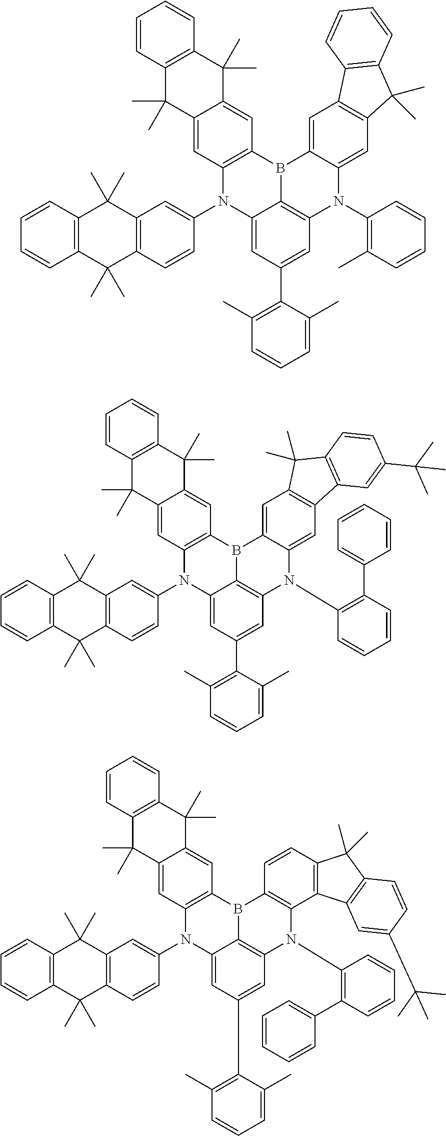 [SMILES: Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)-c1ccccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1ccc(C(C)(C)C)cc1-4 ; Cc1cccc(C)c1-c1cc2c3c(c1)N(c1ccccc1-c1ccccc1)c1c(ccc4c1-c1cc(C(C)(C)C)ccc1C4(C)C)B3c1cc3c(cc1N2c1ccc2c(c1)C(C)(C)c1ccccc1C2(C)C)C(C)(C)c1ccccc1C3(C)C]

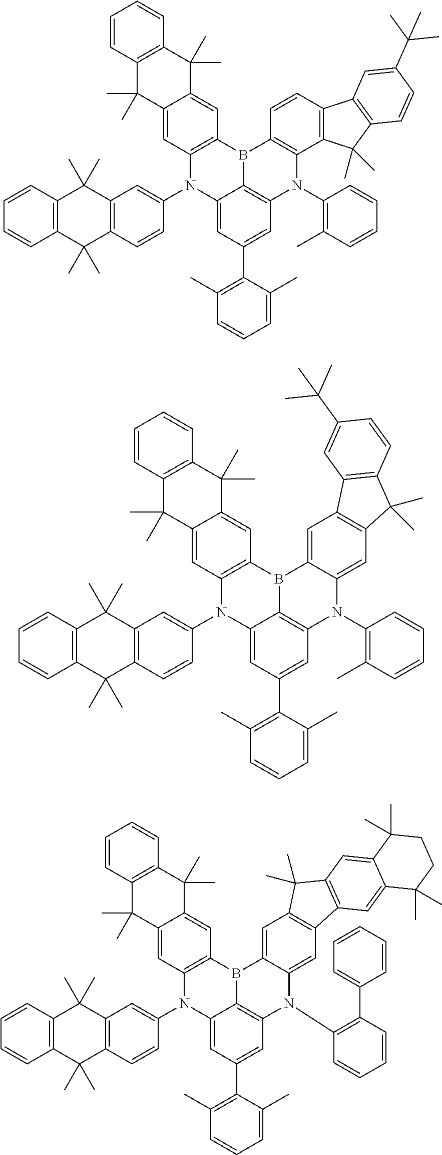 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)C(C)(C)c1ccc(C(C)(C)C)cc1-3 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)-c1cc(C(C)(C)C)ccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1cc2c(cc1-4)C(C)(C)CCC2(C)C]

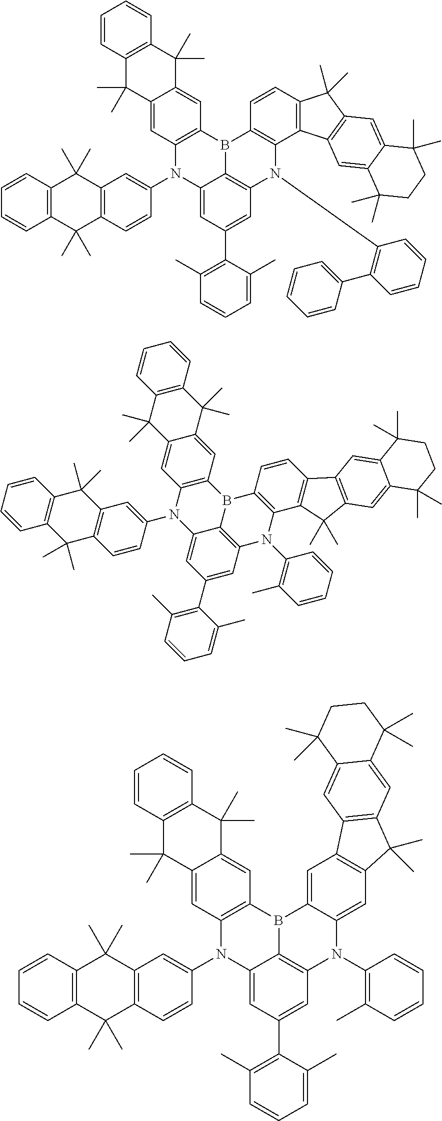 [SMILES: Cc1cccc(C)c1-c1cc2c3c(c1)N(c1ccccc1-c1ccccc1)c1c(ccc4c1-c1cc5c(cc1C4(C)C)C(C)(C)CCC5(C)C)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)C(C)(C)c1cc2c(cc1-3)C(C)(C)CCC2(C)C ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)-c1cc2c(cc1C3(C)C)C(C)(C)CCC2(C)C]

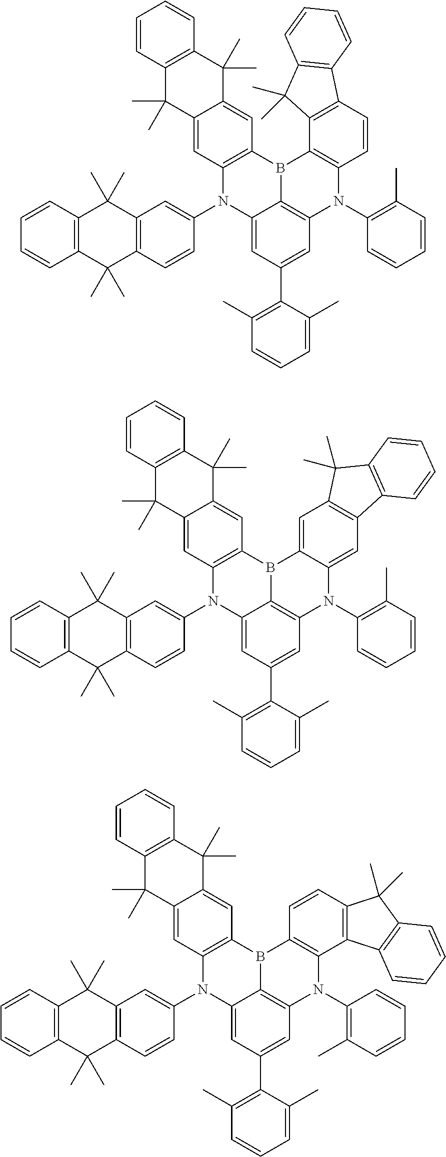 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccccc2-1 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)C(C)(C)c1ccccc1-3 ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)-c1ccccc1C3(C)C]

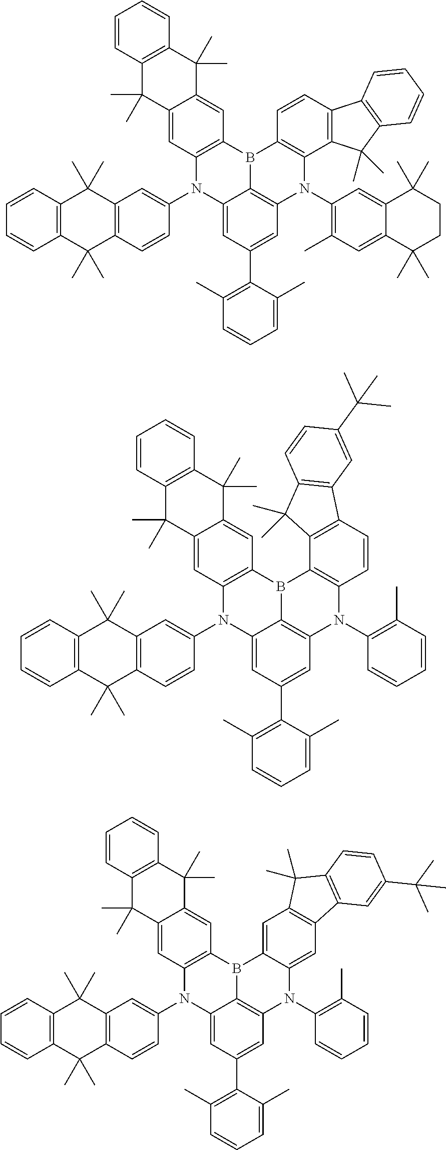 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1ccccc1-4)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccc(C(C)(C)C)cc2-1 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)C(C)(C)c1ccc(C(C)(C)C)cc1-3]

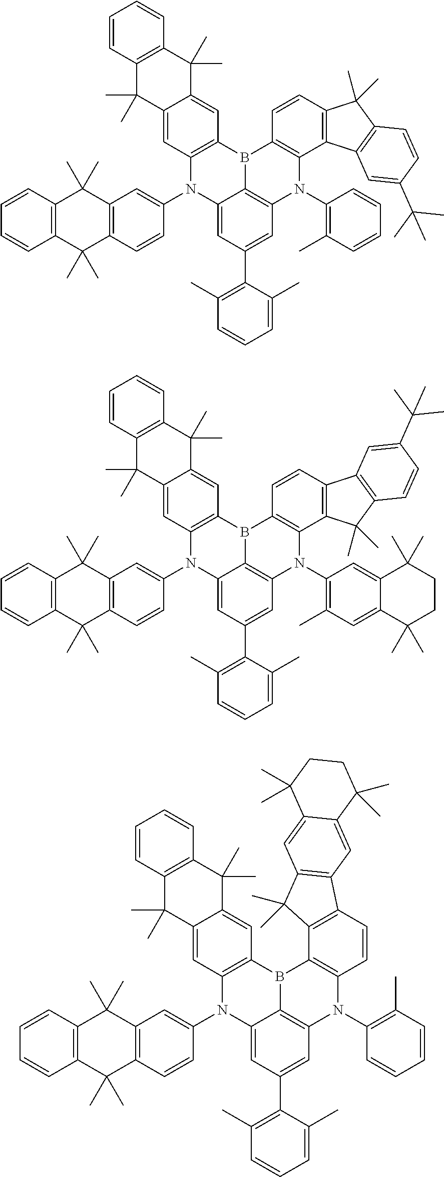 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)-c1cc(C(C)(C)C)ccc1C3(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1ccc(C(C)(C)C)cc1-4)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2cc3c(cc2-1)C(C)(C)CCC3(C)C]

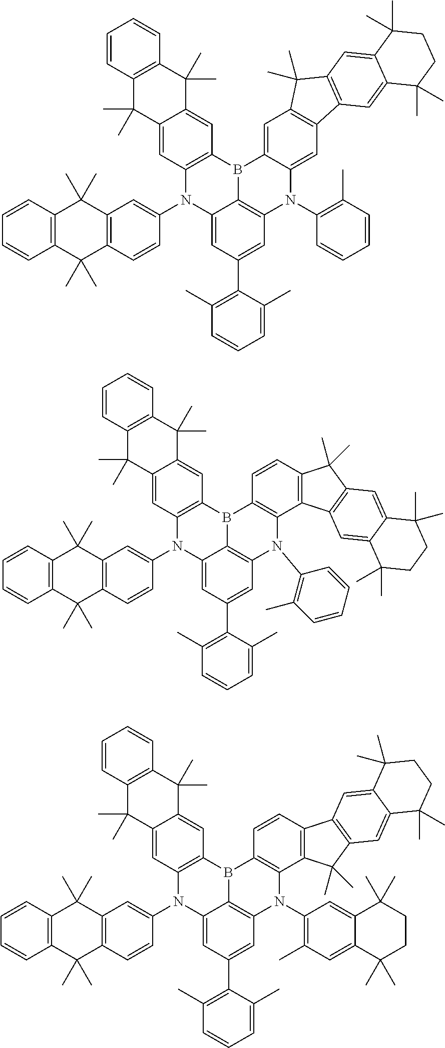 [SMILES: Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)C(C)(C)c1cc2c(cc1-3)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)-c1cc2c(cc1C3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1cc3c(cc1-4)C(C)(C)CCC3(C)C)C(C)(C)CCC2(C)C]

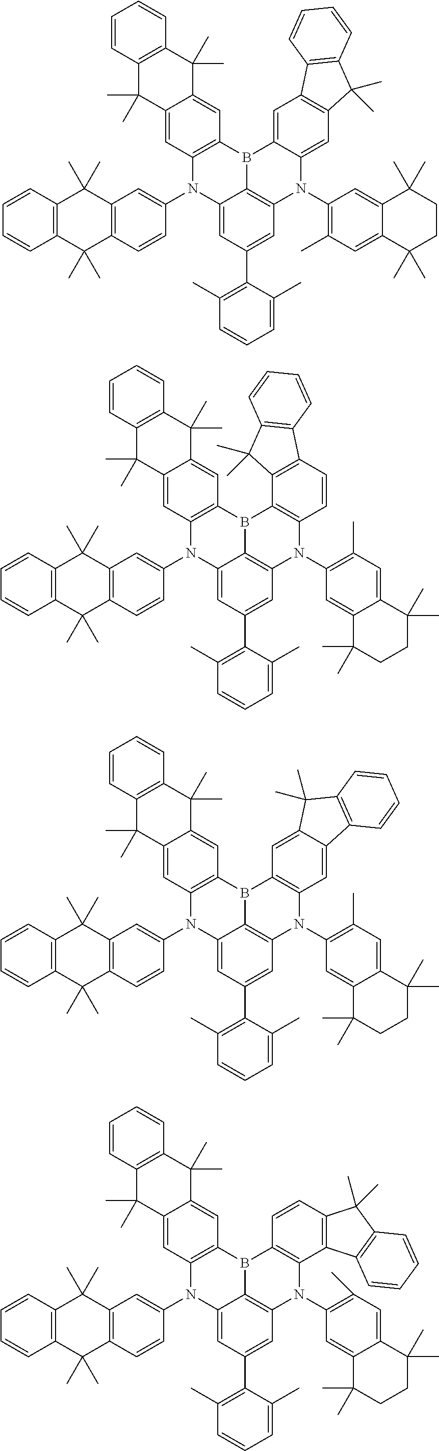

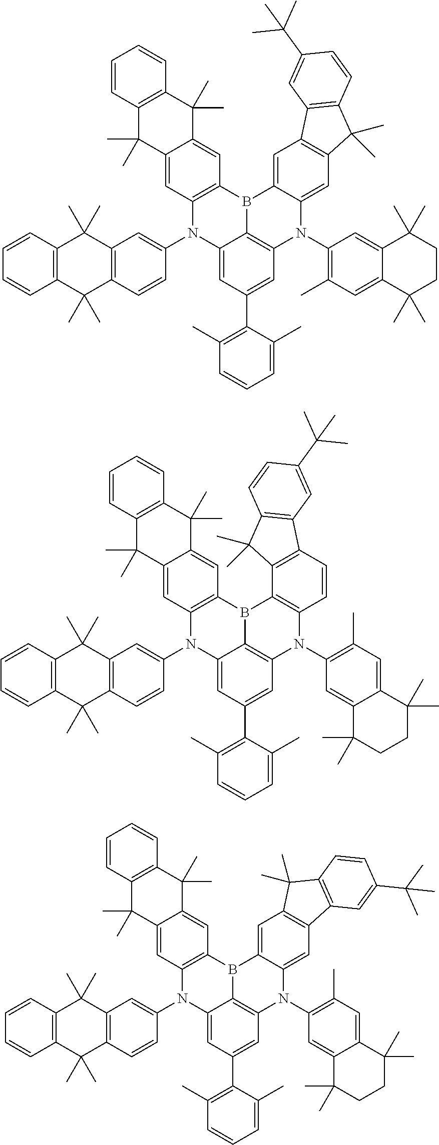 [SMILES: Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)-c1cc(C(C)(C)C)ccc1C4(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3C(C)(C)c3ccc(C(C)(C)C)cc3-1)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)C(C)(C)c1ccc(C(C)(C)C)cc1-4)C(C)(C)CCC2(C)C]

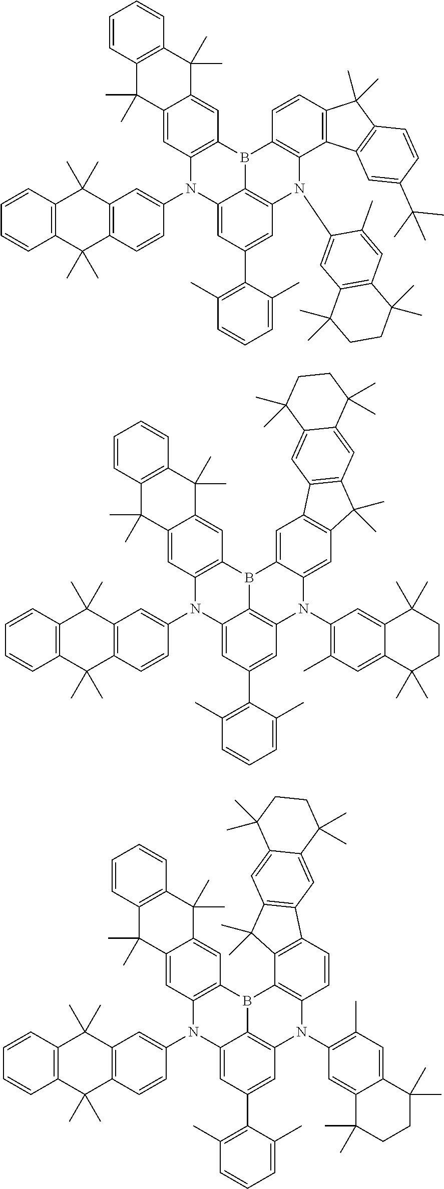

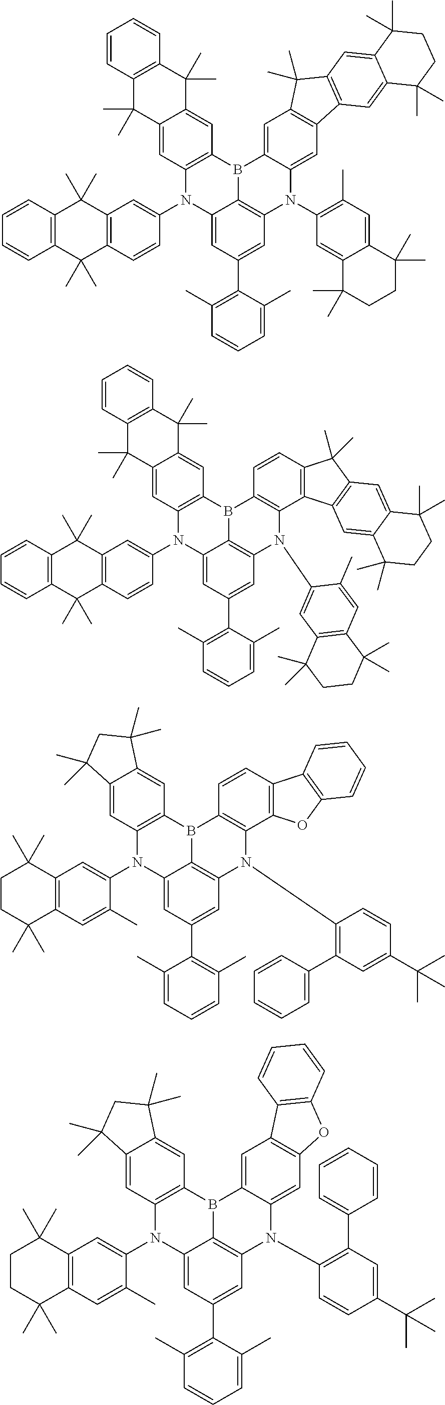

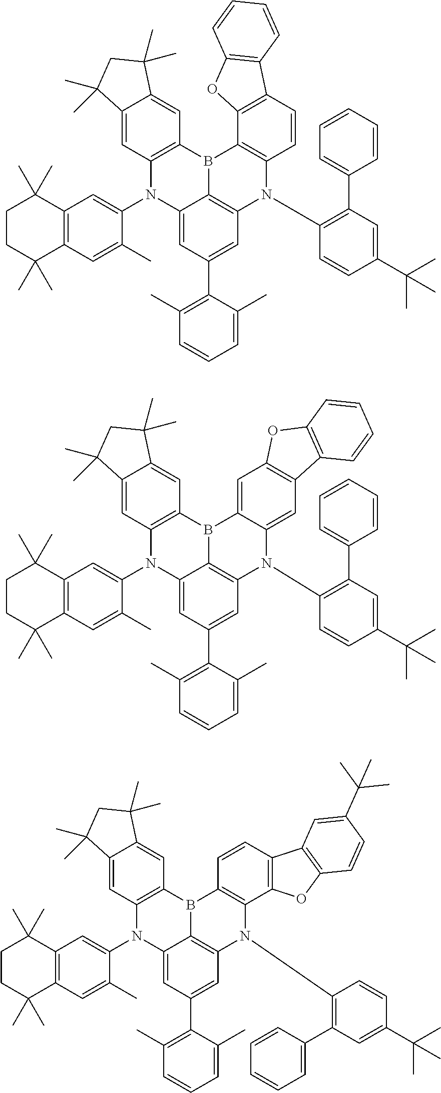 [SMILES: Cc1cc2c(cc1N1c3cc4c(cc3B3c5c1cc(-c1c(C)cccc1C)cc5N(c1ccc(C(C)(C)C)cc1-c1ccccc1)c1ccc5c(oc6ccccc65)c13)C(C)(C)CC4(C)C)C(C)(C)CCC2(C)C ; Cc1cc2c(cc1N1c3cc4c(cc3B3c5cc6oc7ccccc7c6cc5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(-c6c(C)cccc6C)cc1c53)C(C)(C)CC4(C)C)C(C)(C)CCC2(C)C]

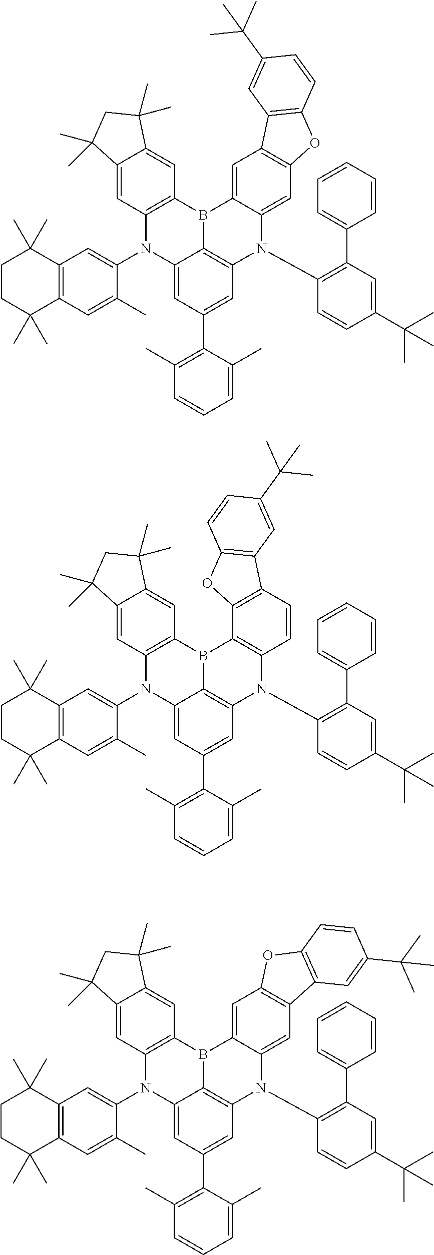 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(oc6ccc(C(C)(C)C)cc65)c13)C(C)(C)CC4(C)C)C(C)(C)CCC2(C)C ; Cc1cc2c(cc1N1c3cc4c(cc3B3c5cc6oc7ccc(C(C)(C)C)cc7c6cc5N(c5ccc(C(C)(C)C)cc5-c5ccccc5)c5cc(-c6c(C)cccc6C)cc1c53)C(C)(C)CC4(C)C)C(C)(C)CCC2(C)C]

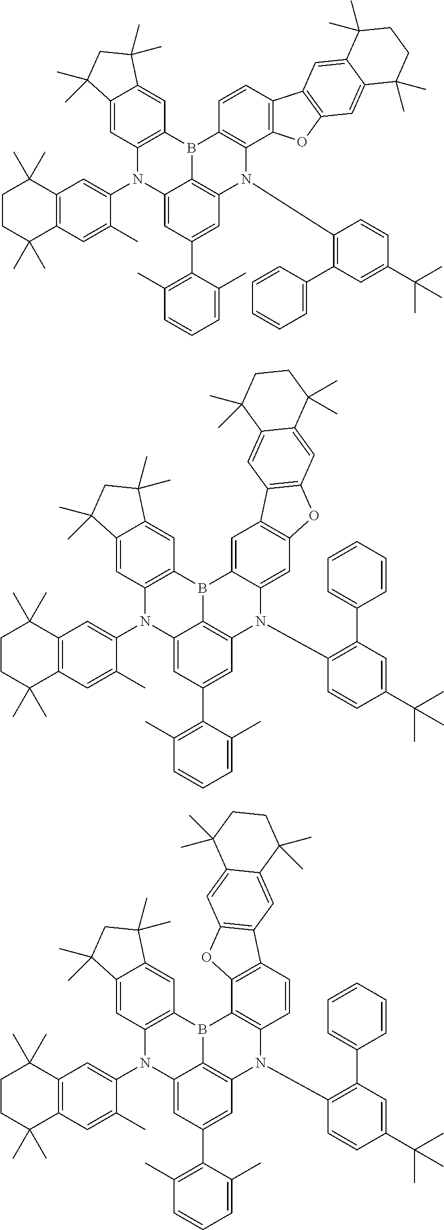

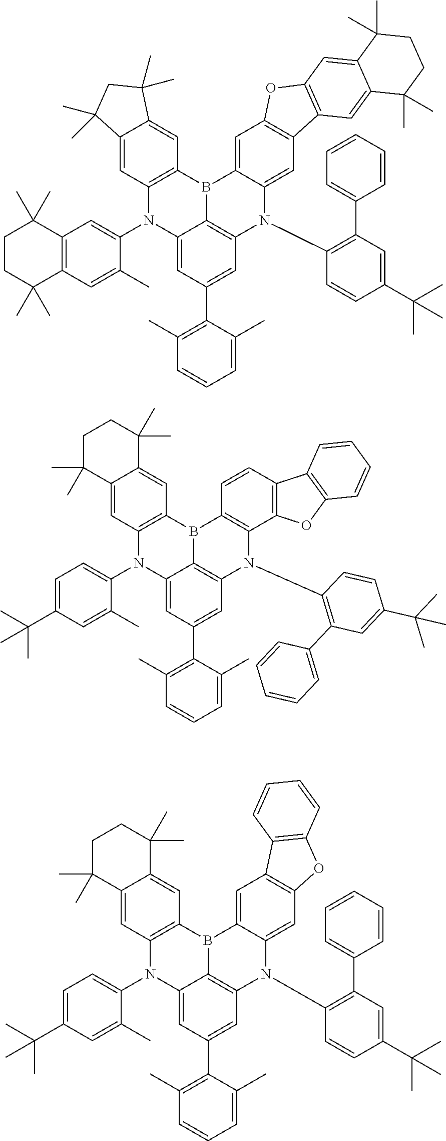

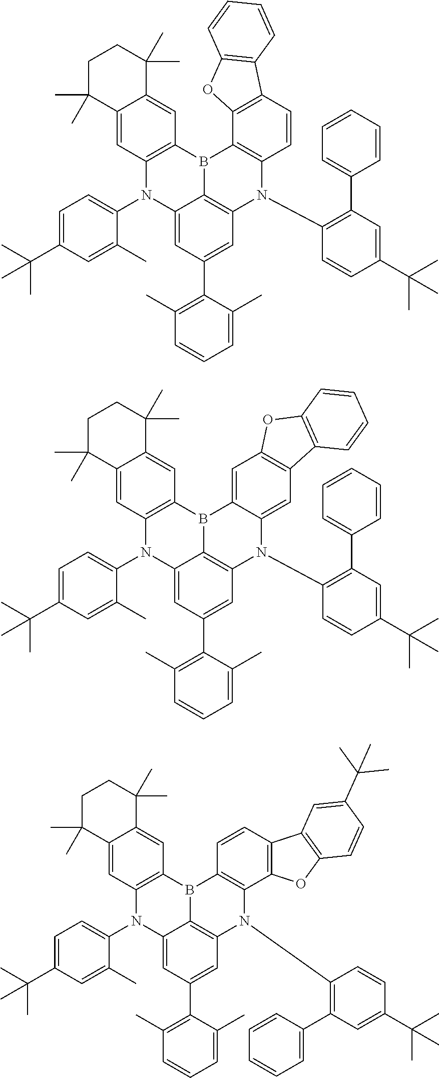

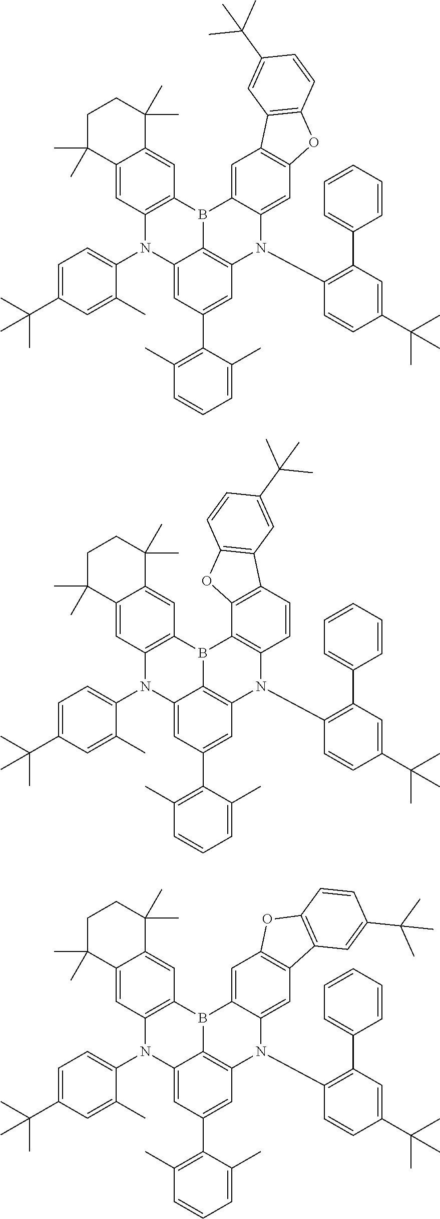

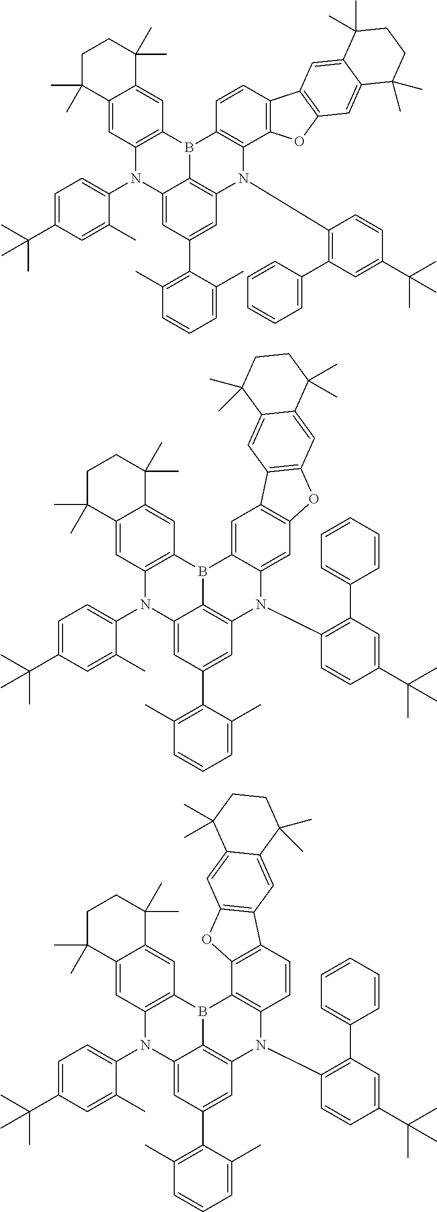

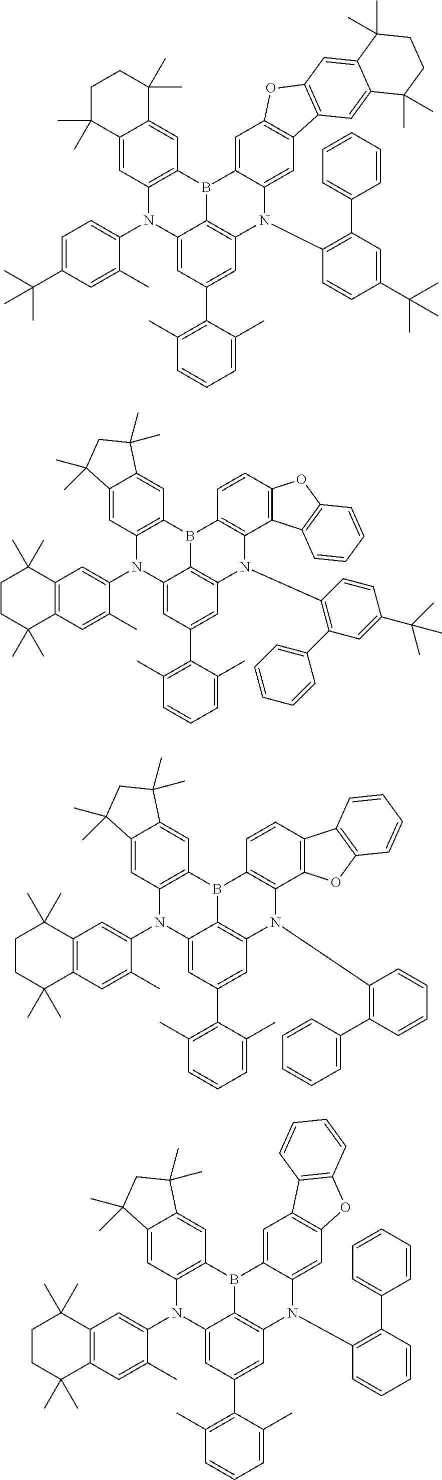

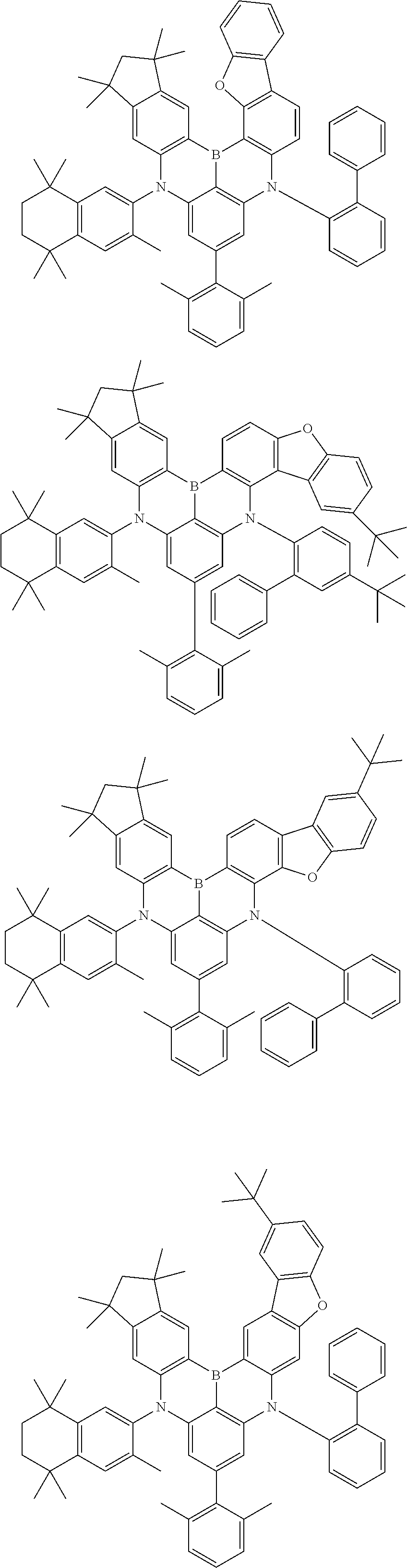

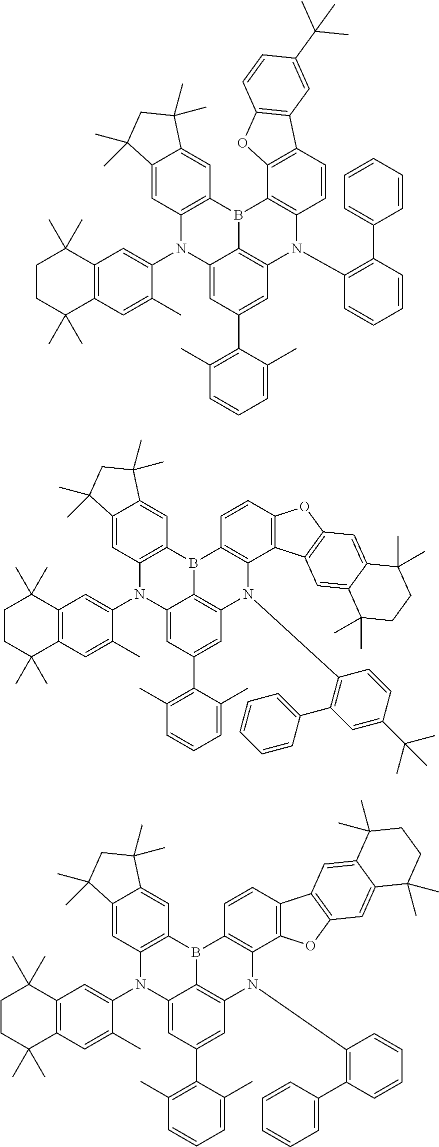

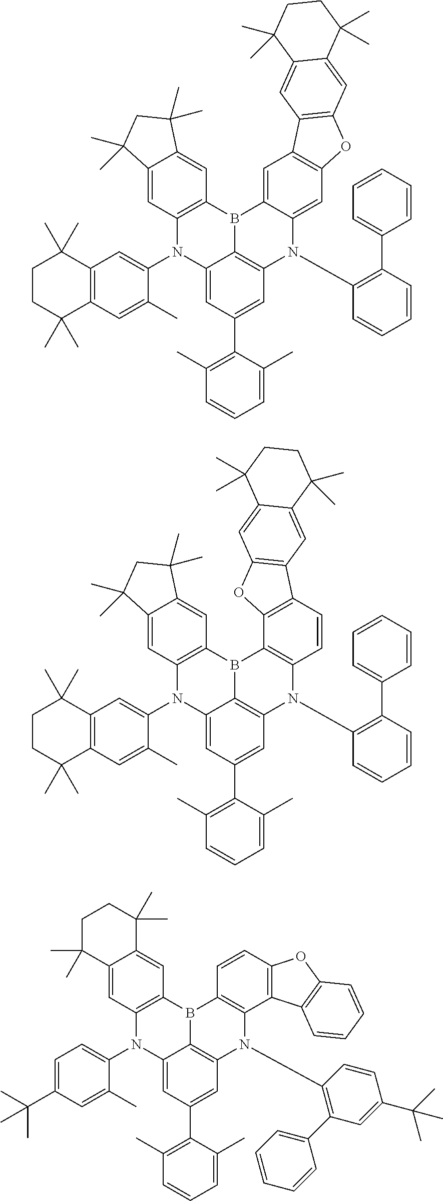

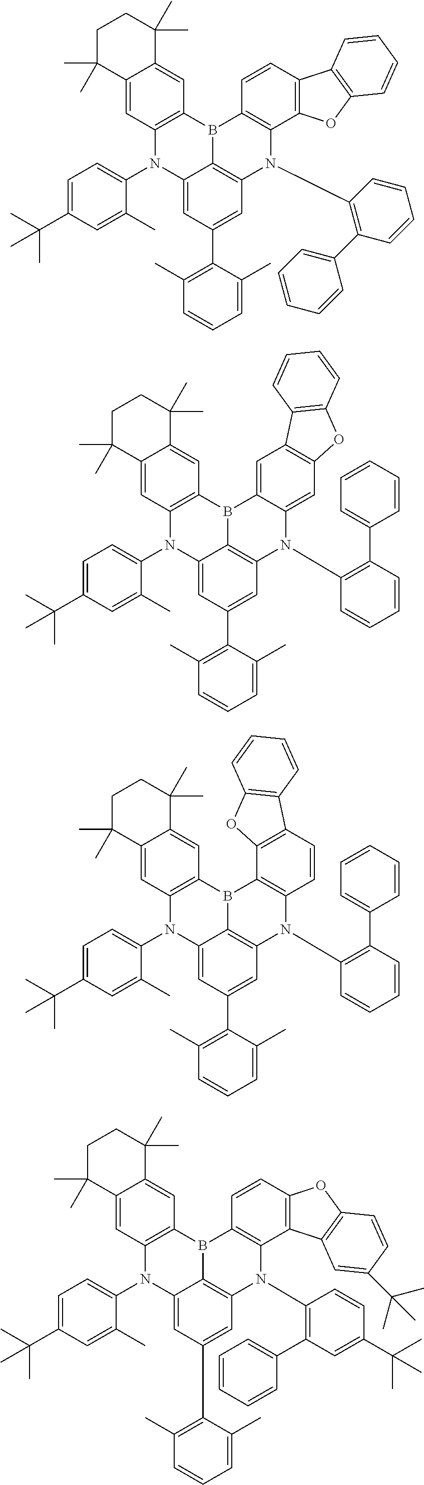

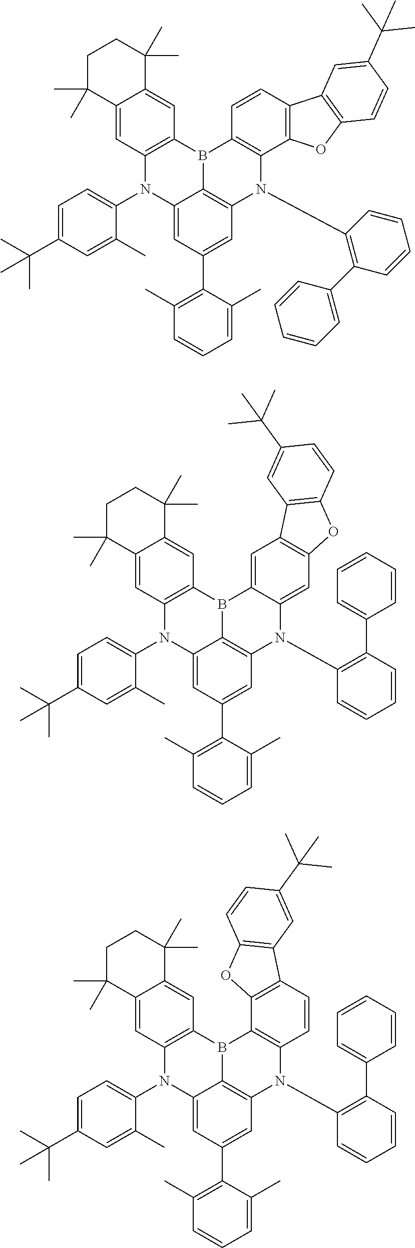

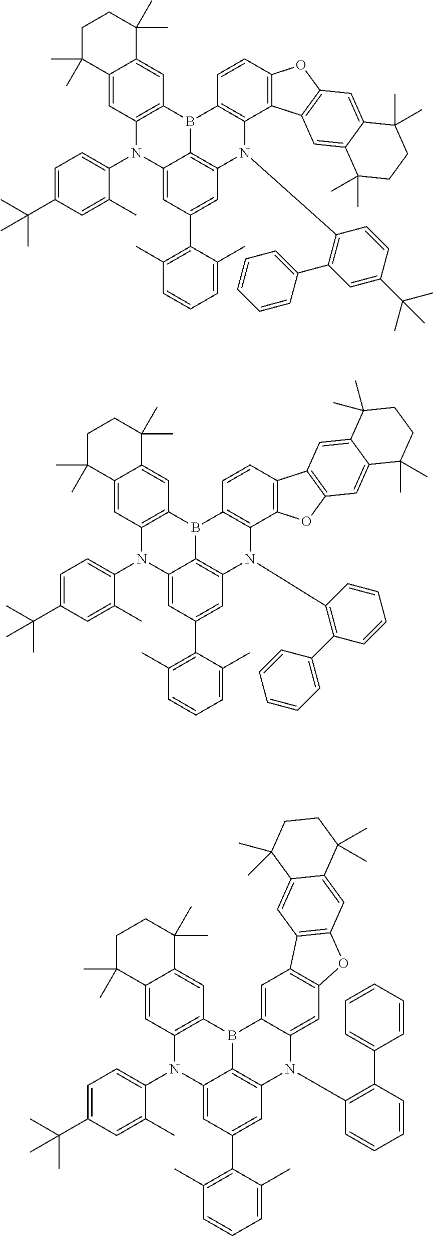

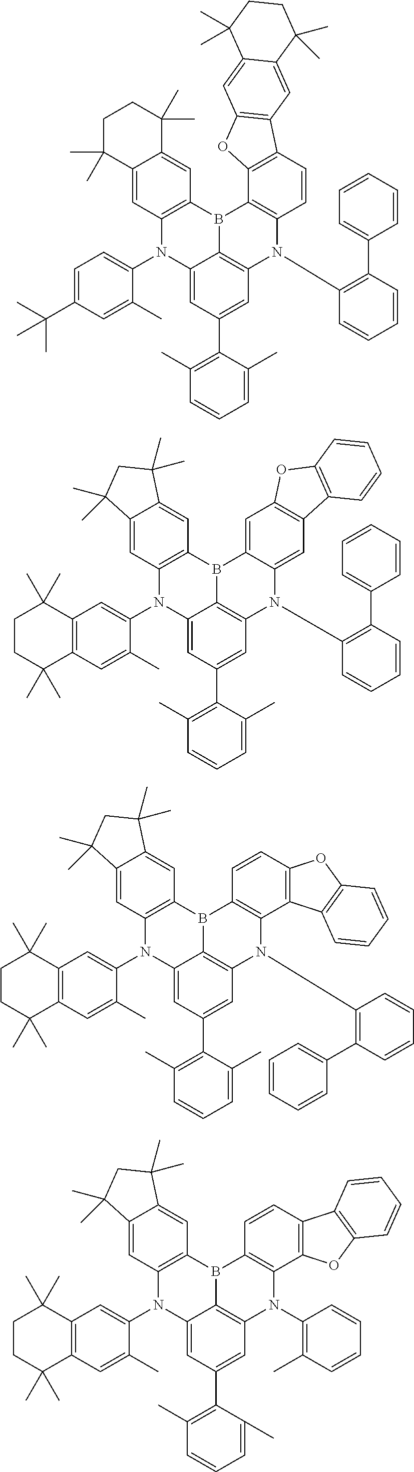

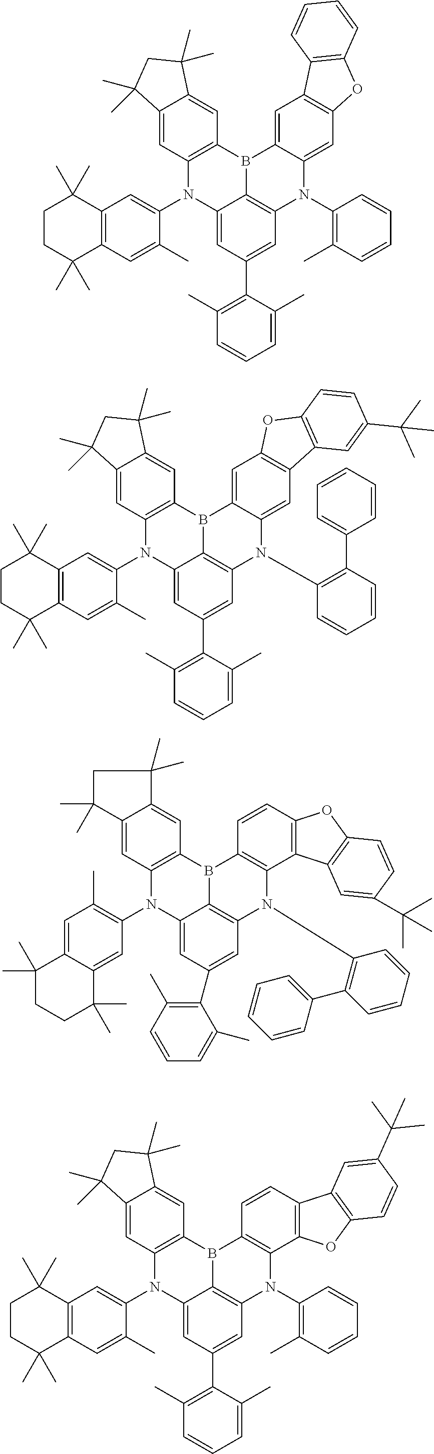

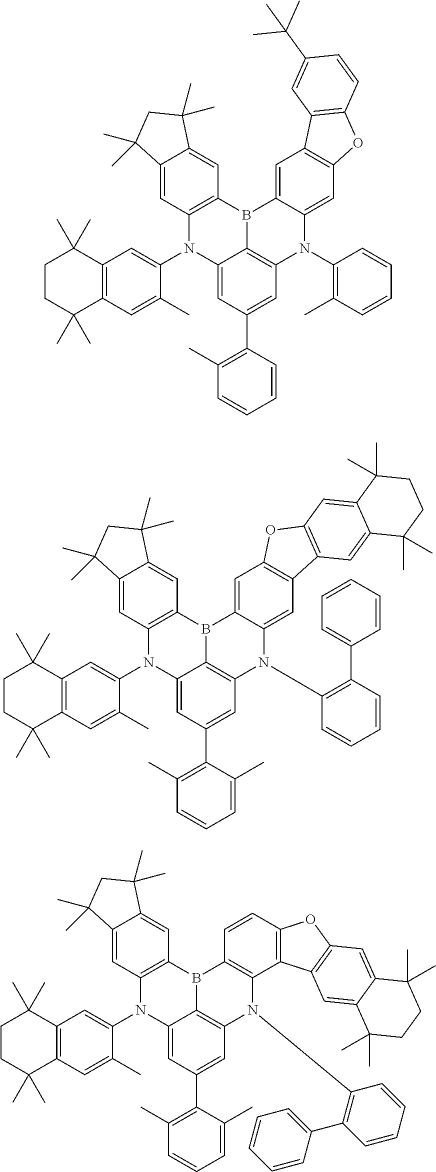 [SMILES: Cc1ccccc1-c1cc2c3c(c1)N(c1ccccc1C)c1cc4oc5ccc(C(C)(C)C)cc5c4cc1B3c1cc3c(cc1N2c1cc2c(cc1C)C(C)(C)CCC2(C)C)C(C)(C)CC3(C)C ; Cc1cc2c(cc1N1c3cc4c(cc3B3c5cc6oc7cc8c(cc7c6cc5N(c5ccccc5-c5ccccc5)c5cc(-c6c(C)cccc6C)cc1c53)C(C)(C)CCC8(C)C)C(C)(C)CC4(C)C)C(C)(C)CCC2(C)C ; Cc1cc2c(cc1N1c3cc4c(cc3B3c5ccc6oc7cc8c(cc7c6c5N(c5ccccc5-c5ccccc5)c5cc(-c6c(C)cccc6C)cc1c53)C(C)(C)CCC8(C)C)C(C)(C)CC4(C)C)C(C)(C)CCC2(C)C]

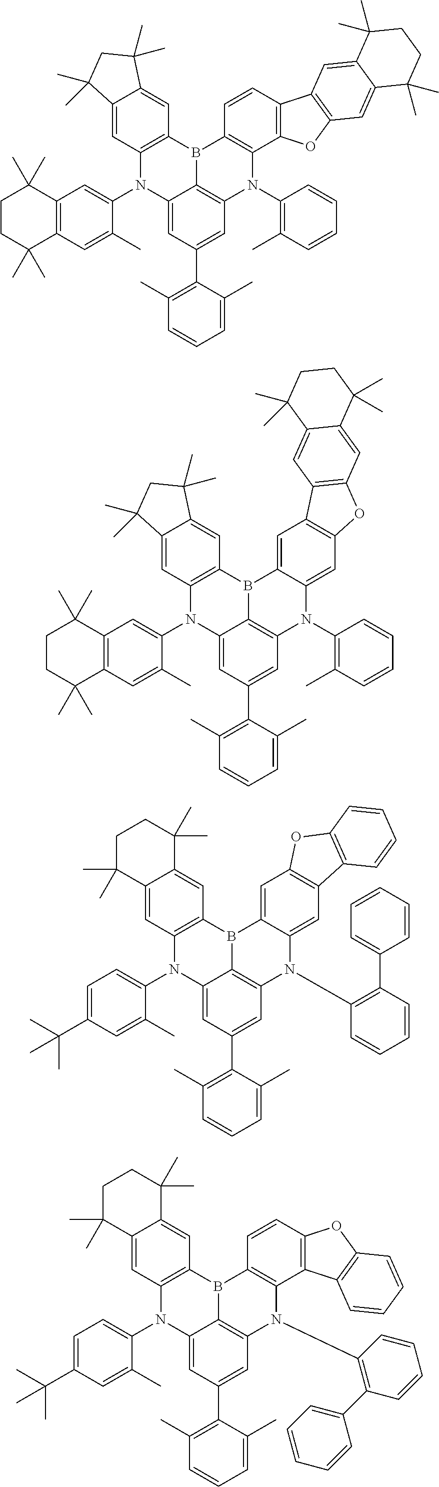

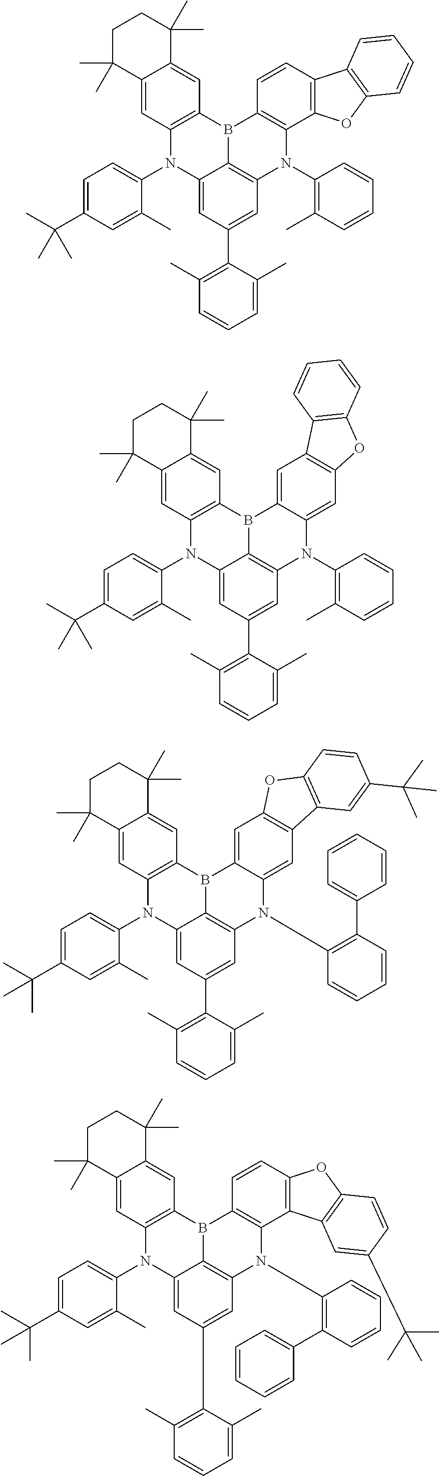

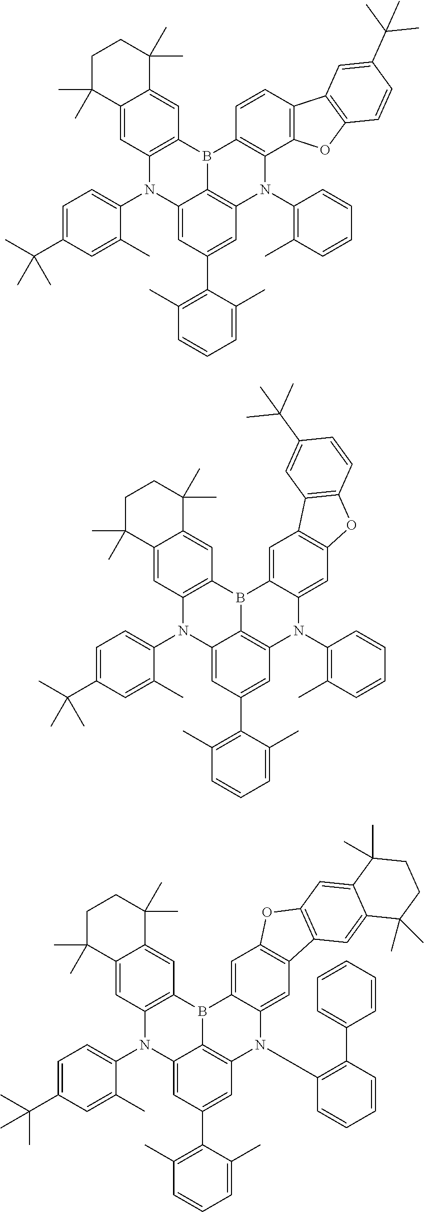

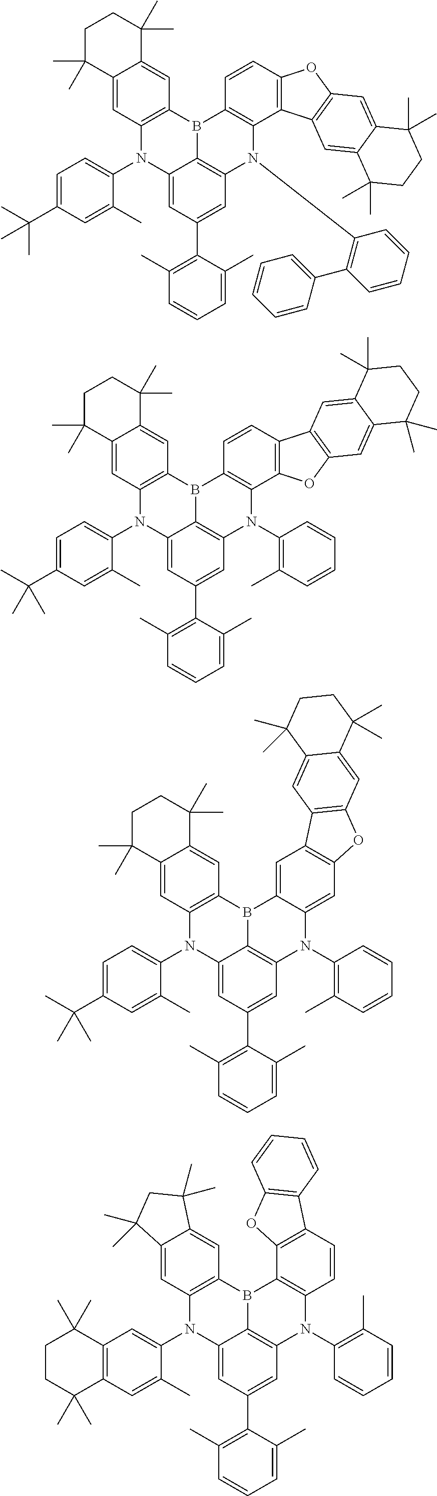

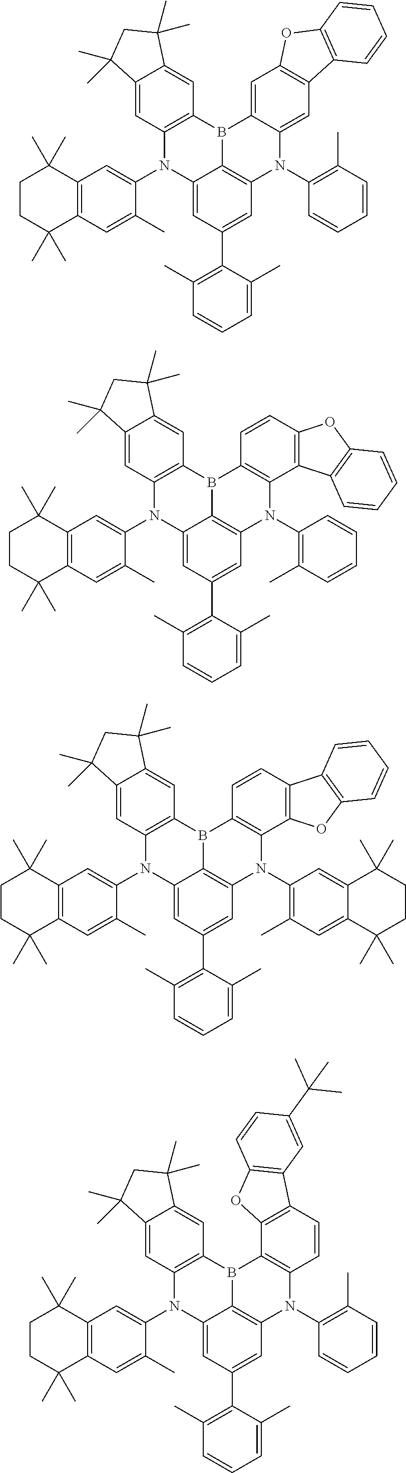 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)oc1ccccc13 ; Cc1cc2c(cc1N1c3cc4c(cc3B3c5ccc6oc7ccccc7c6c5N(c5ccccc5C)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(oc6ccc(C(C)(C)C)cc65)c13)C(C)(C)CC4(C)C)C(C)(C)CCC2(C)C]

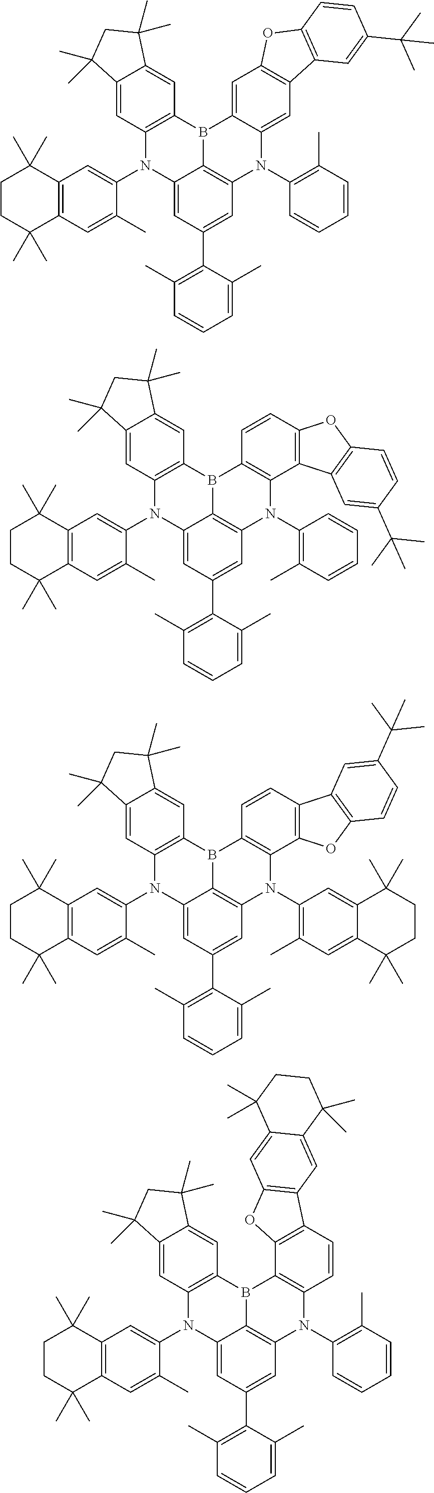

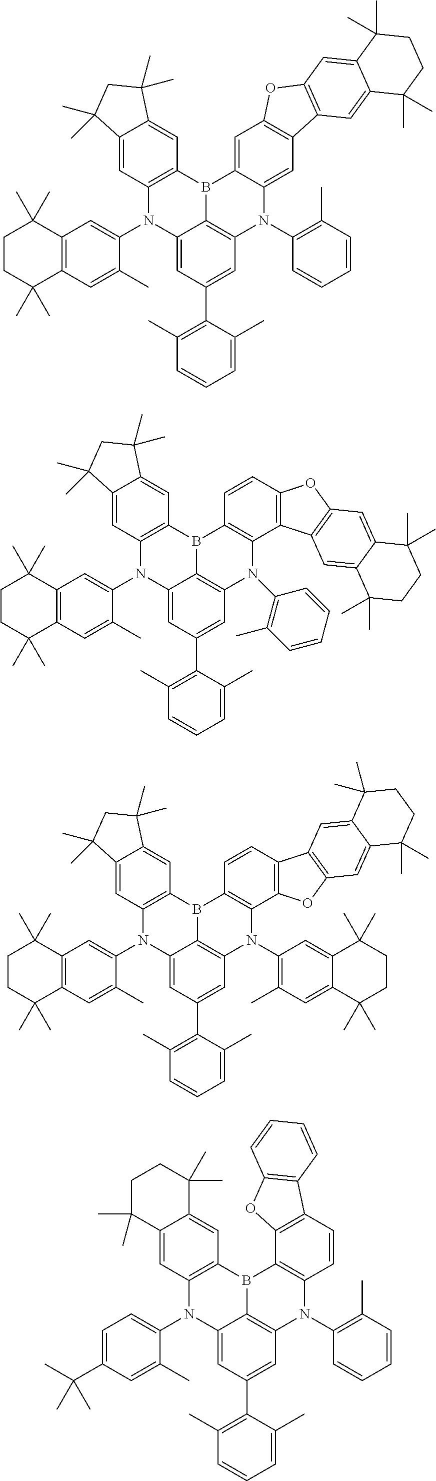

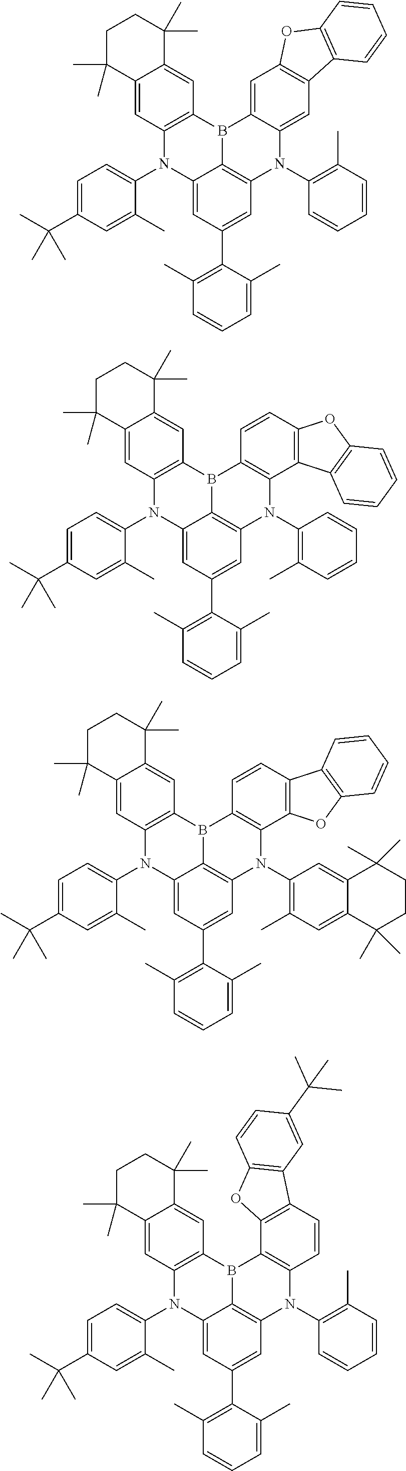

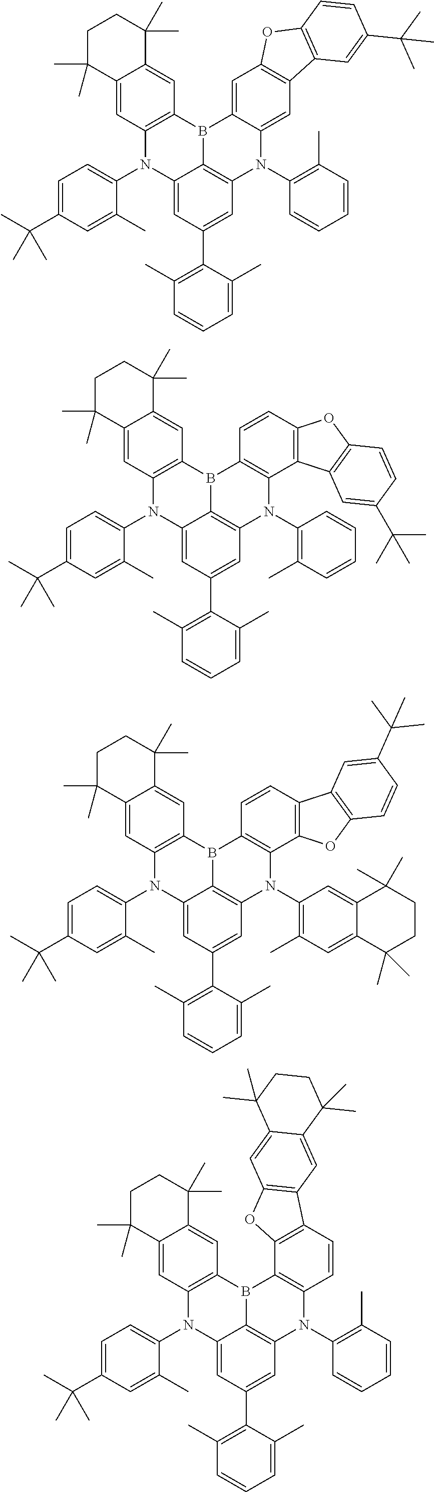

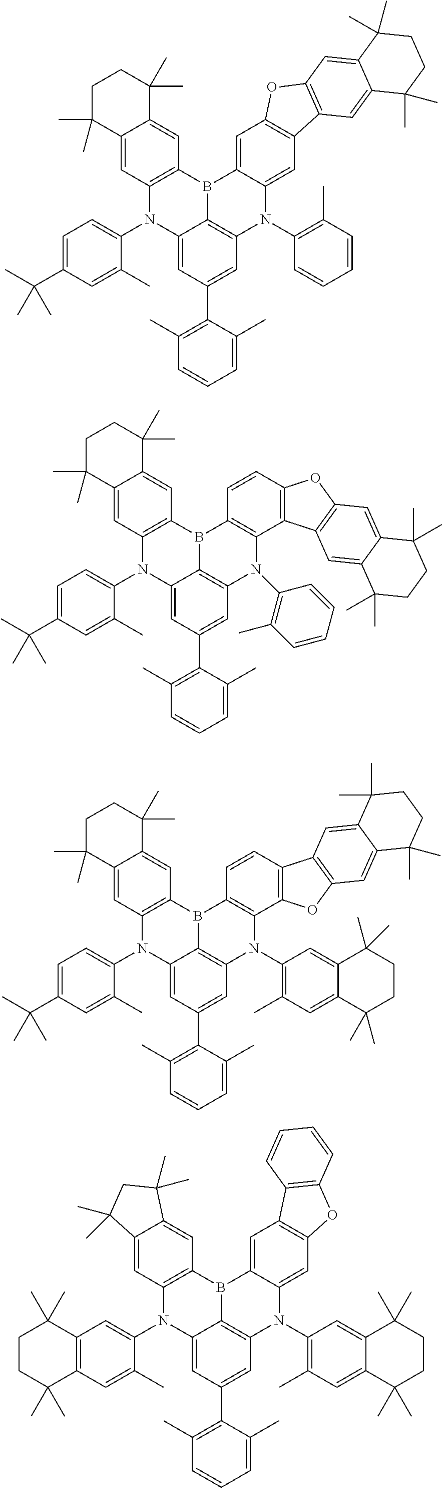

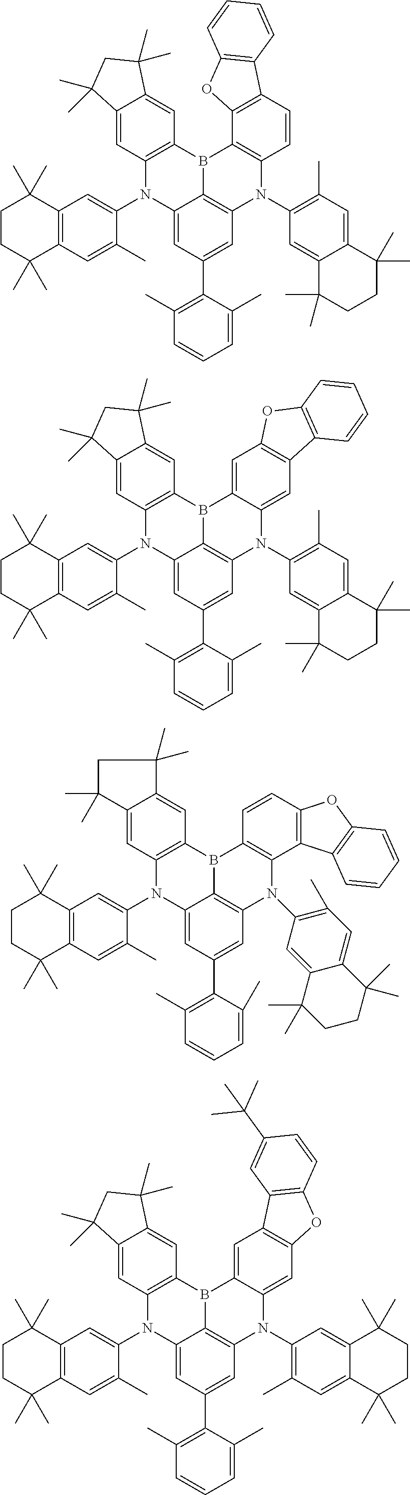

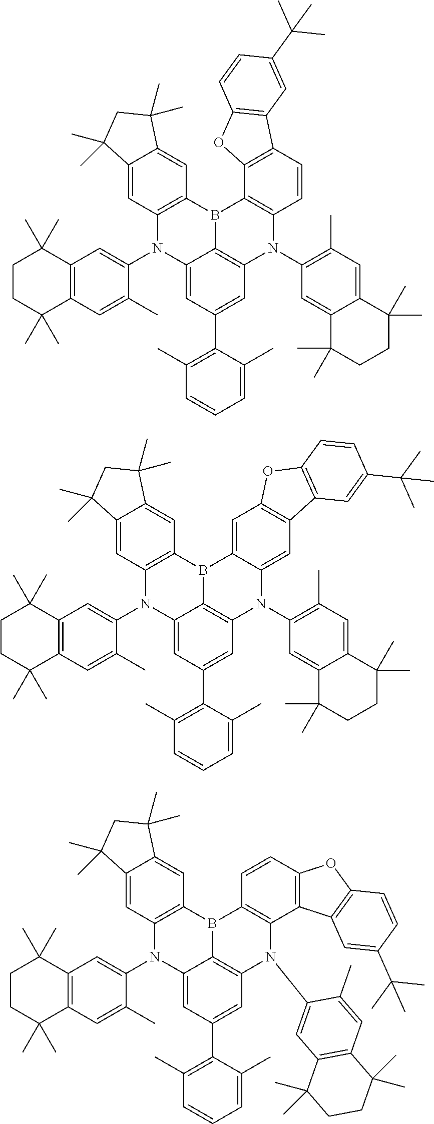

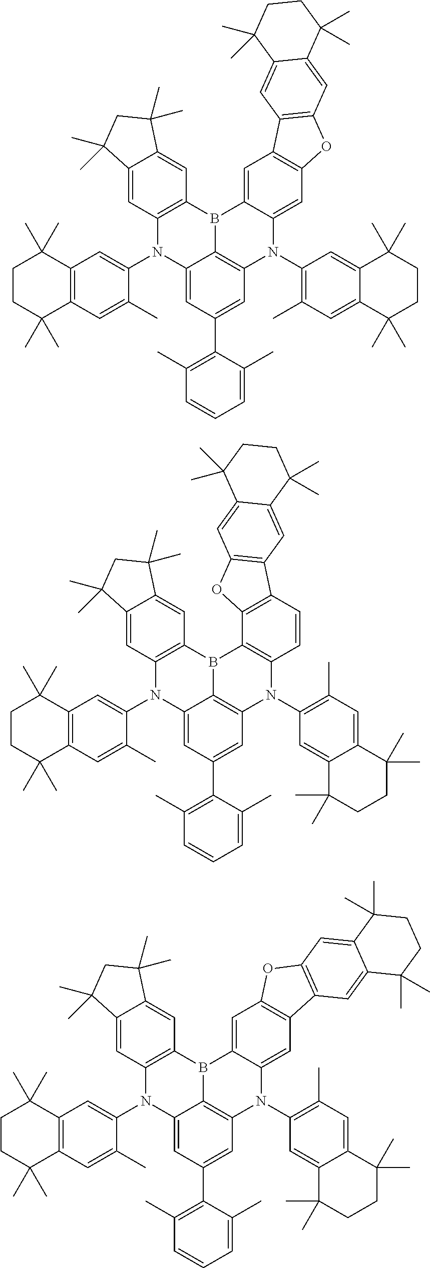

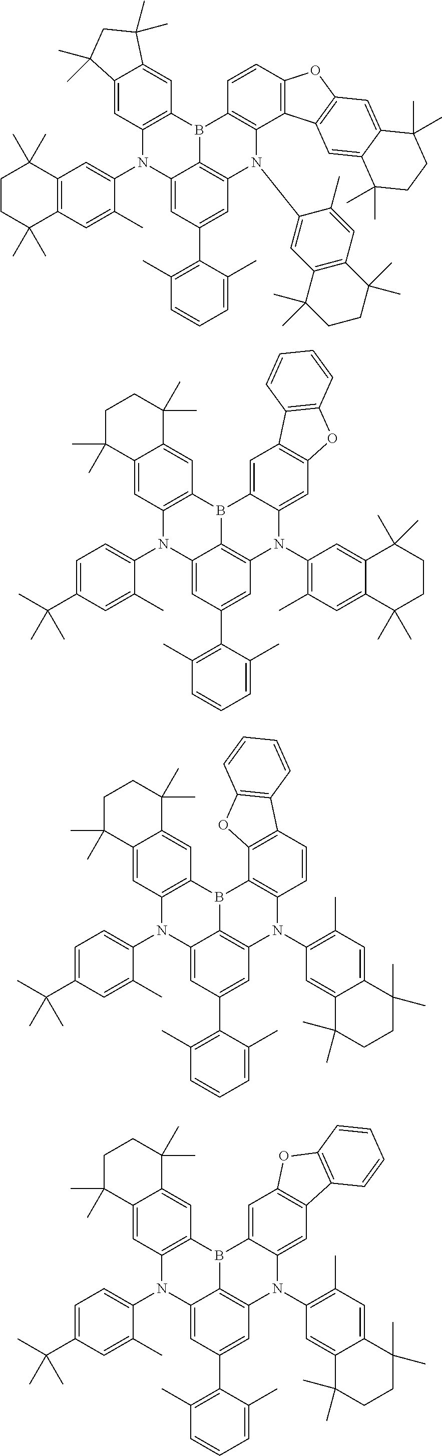

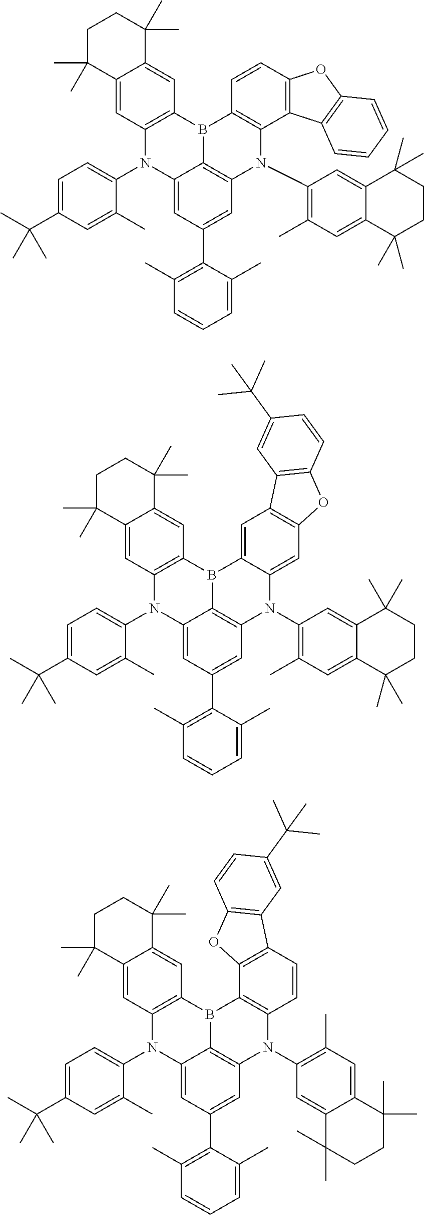

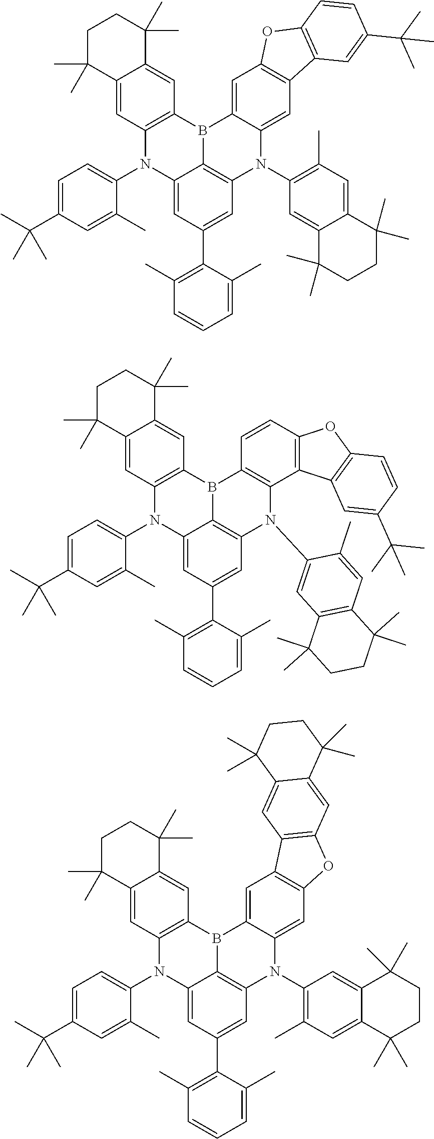

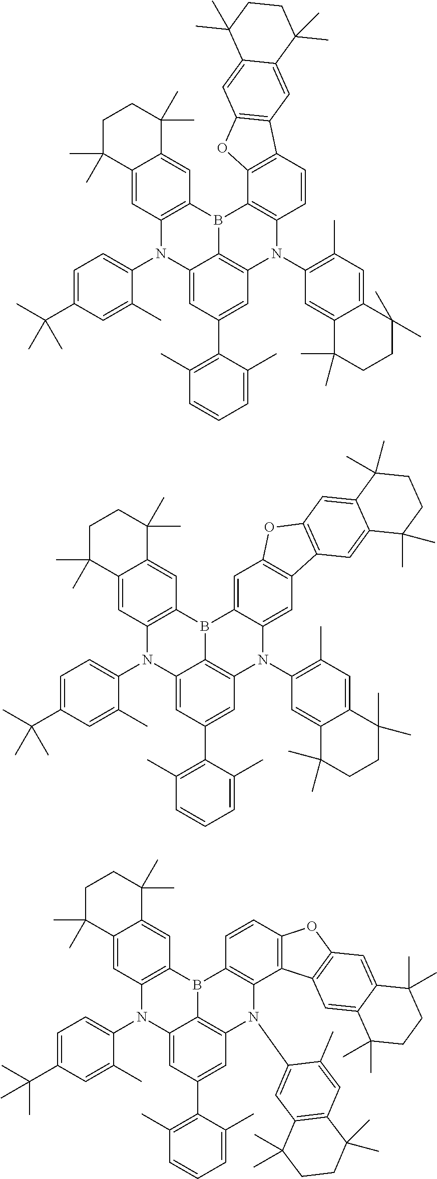

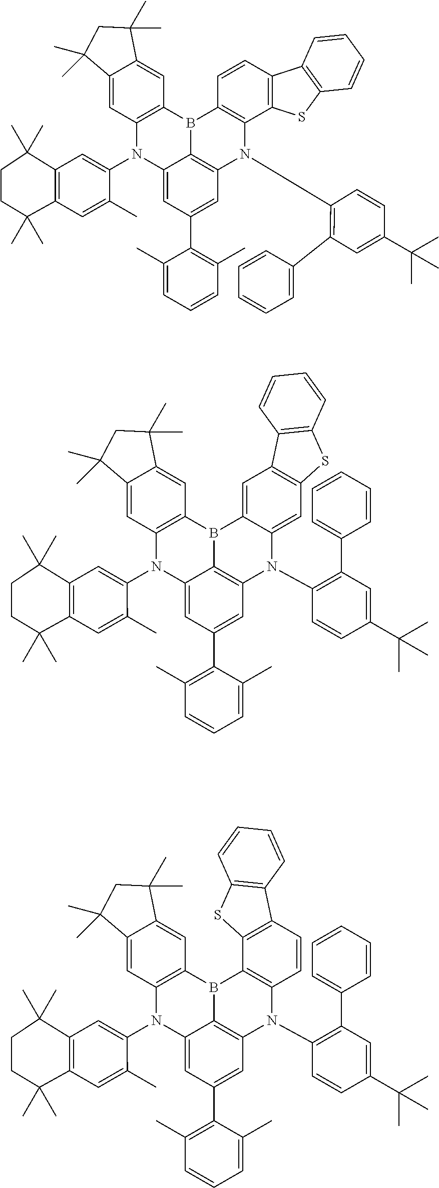 [SMILES: Cc1cc2c(cc1N1c3cc4c(cc3B3c5ccc6c(sc7ccccc76)c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1ccccc16)C(C)(C)CC4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(sc6ccccc65)c13)C(C)(C)CC4(C)C)C(C)(C)CCC2(C)C]

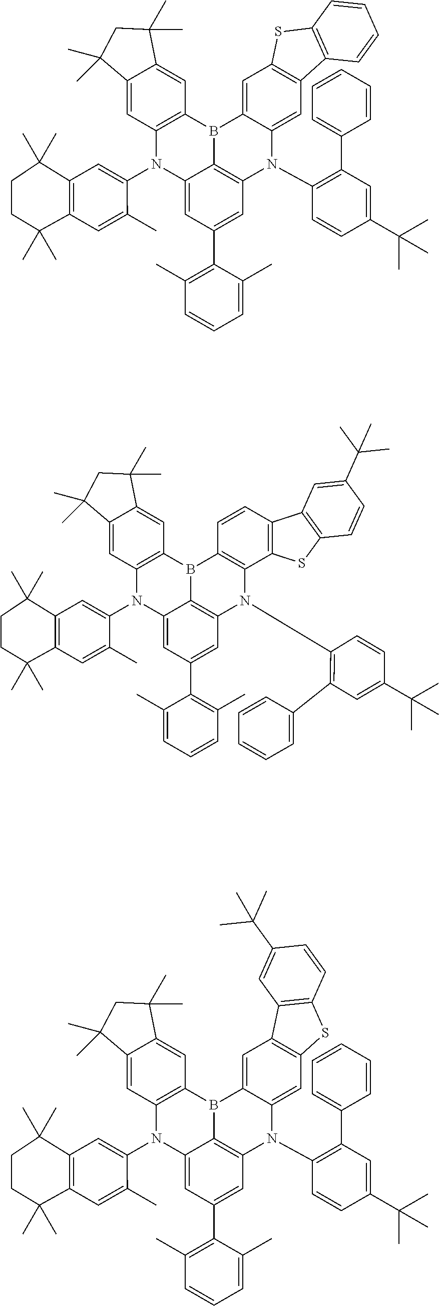 [SMILES: Cc1cc2c(cc1N1c3cc4c(cc3B3c5cc6sc7ccccc7c6cc5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1ccc(C(C)(C)C)cc16)C(C)(C)CC4(C)C)C(C)(C)CCC2(C)C]

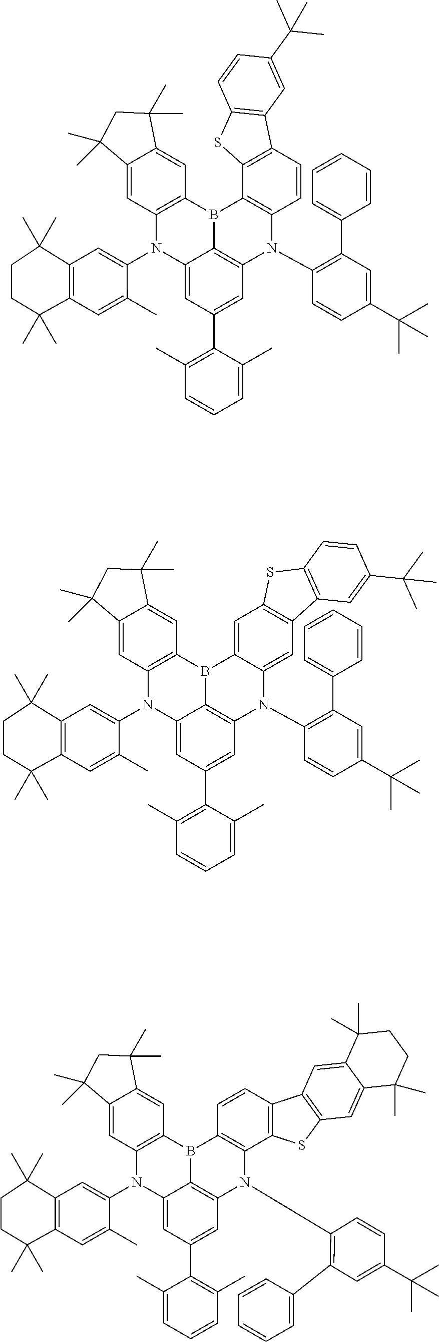 [SMILES: Cc1cc2c(cc1N1c3cc4c(cc3B3c5c1cc(-c1c(C)cccc1C)cc5N(c1ccc(C(C)(C)C)cc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(-c6c(C)cccc6C)cc1c53)C(C)(C)CC4(C)C)C(C)(C)CCC2(C)C]

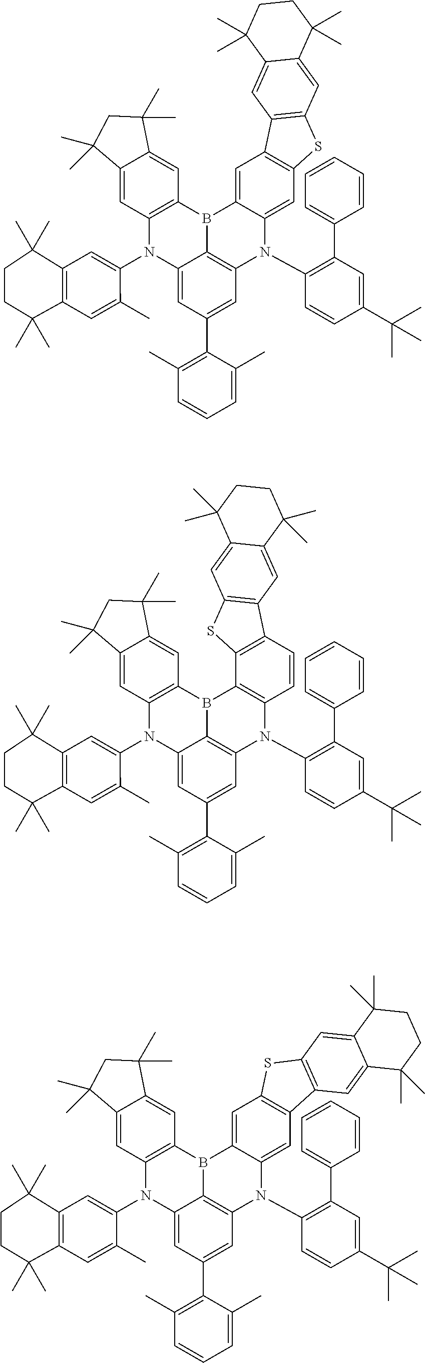 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)sc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(sc6cc7c(cc65)C(C)(C)CCC7(C)C)c13)C(C)(C)CC4(C)C)C(C)(C)CCC2(C)C ; Cc1cc2c(cc1N1c3cc4c(cc3B3c5cc6sc7cc8c(cc7c6cc5N(c5ccc(C(C)(C)C)cc5-c5ccccc5)c5cc(-c6c(C)cccc6C)cc1c53)C(C)(C)CCC8(C)C)C(C)(C)CC4(C)C)C(C)(C)CCC2(C)C]

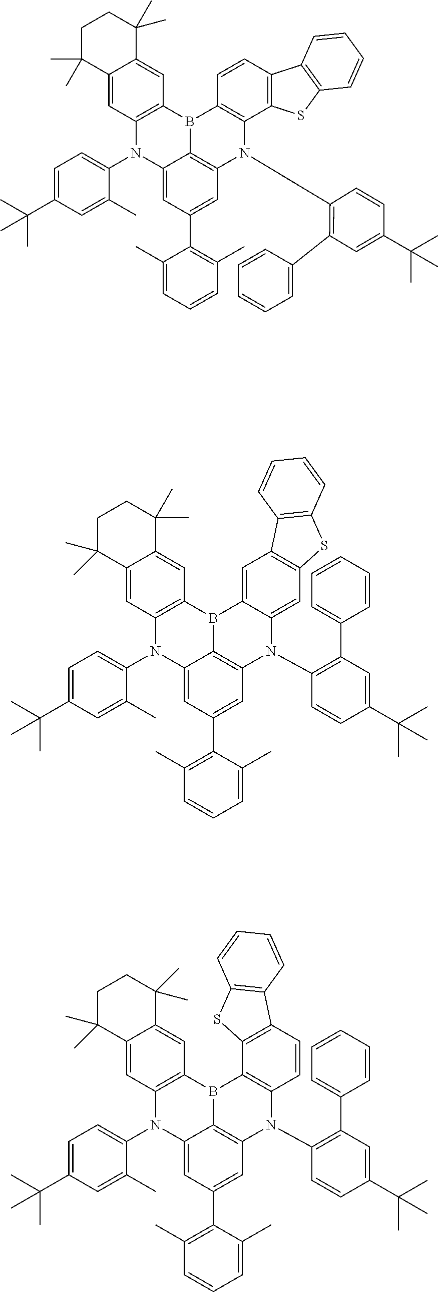

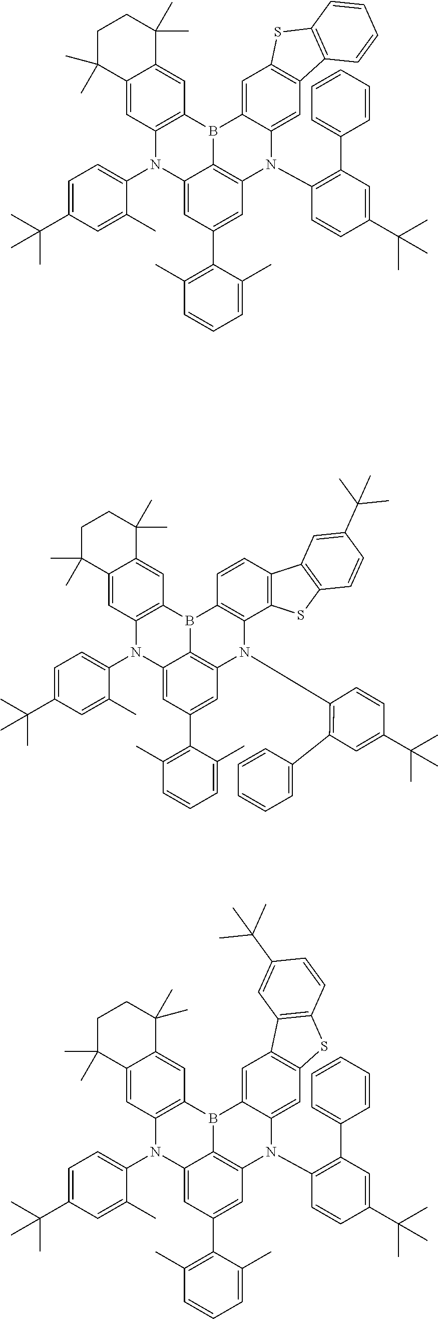

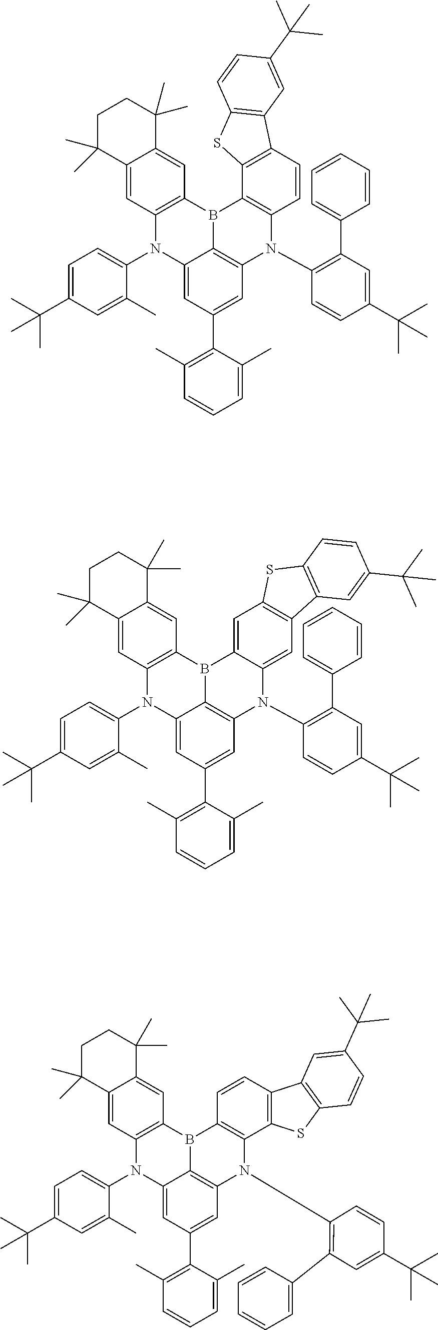

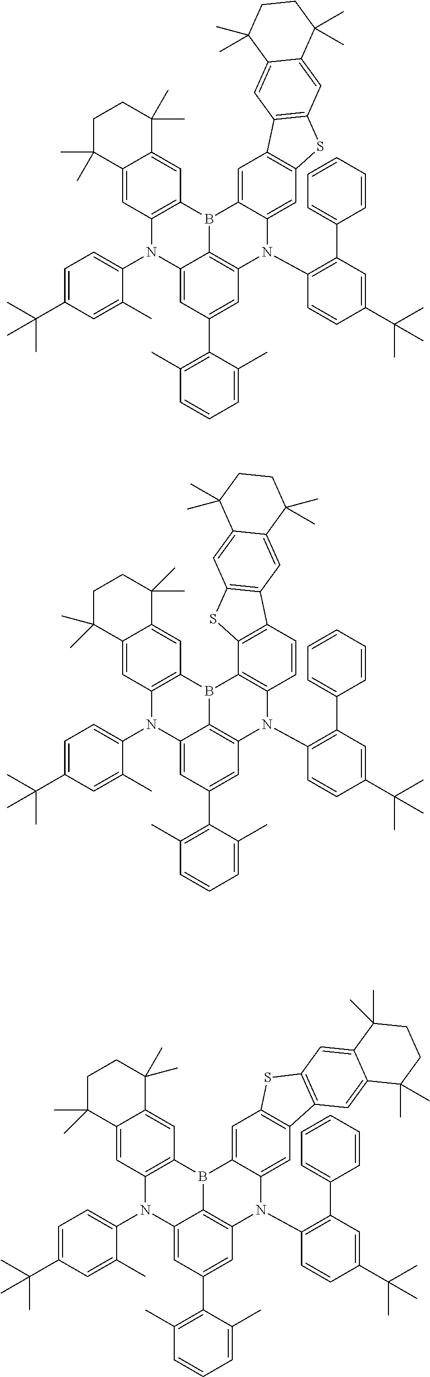

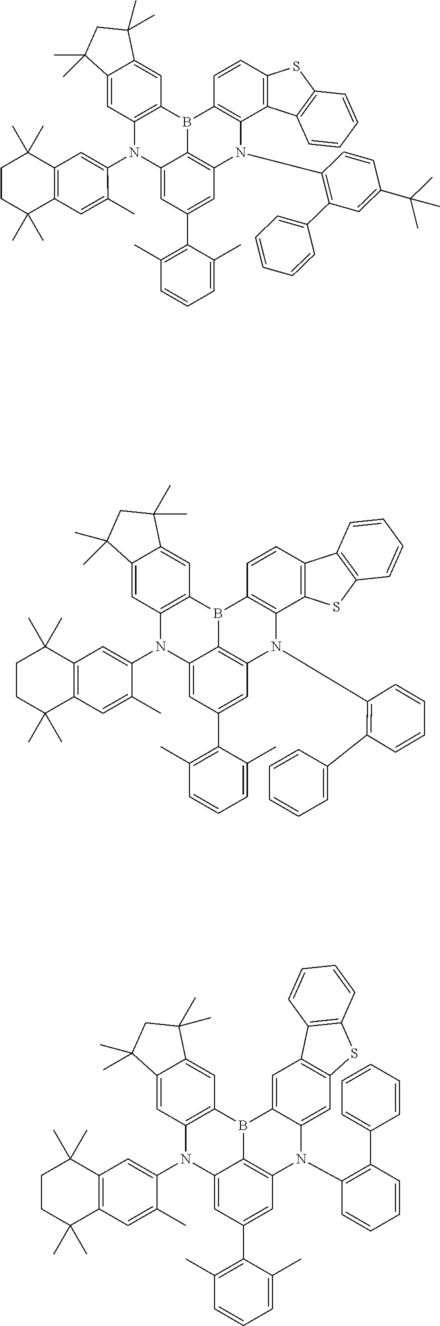 [SMILES: Cc1cc2c(cc1N1c3cc4c(cc3B3c5ccc6sc7ccccc7c6c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)sc1ccccc16)C(C)(C)CC4(C)C)C(C)(C)CCC2(C)C]

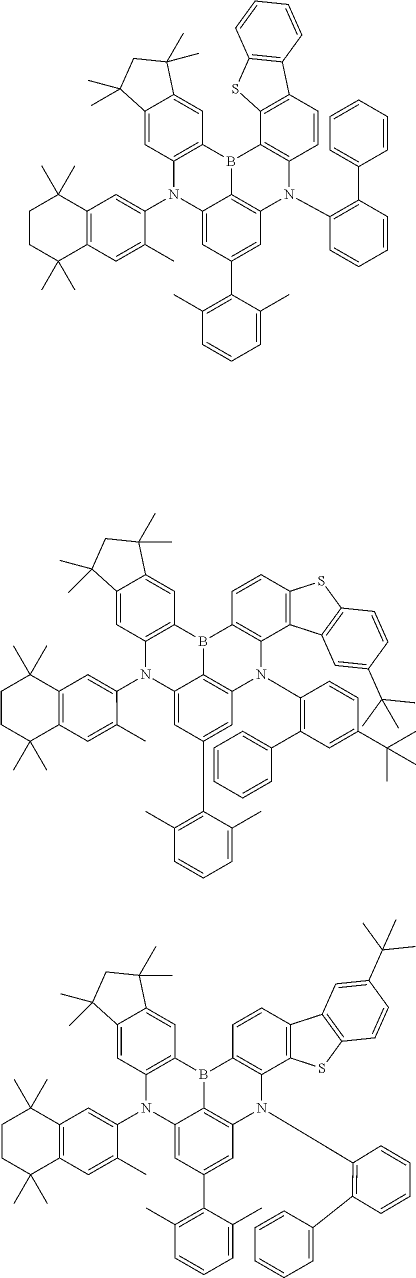 [SMILES: Cc1cc2c(cc1N1c3cc4c(cc3B3c5c1cc(-c1c(C)cccc1C)cc5N(c1ccccc1-c1ccccc1)c1ccc5c(sc6ccccc65)c13)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(-c6c(C)cccc6C)cc1c53)C(C)(C)CC4(C)C)C(C)(C)CCC2(C)C]

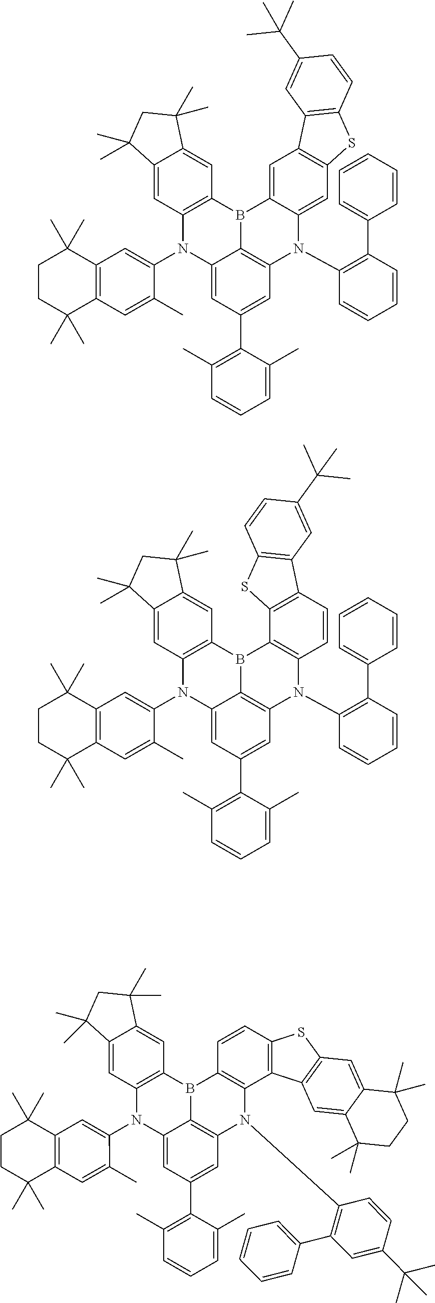 [SMILES: Cc1cc2c(cc1N1c3cc4c(cc3B3c5cc6c(cc5N(c5ccccc5-c5ccccc5)c5cc(-c7c(C)cccc7C)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(-c6c(C)cccc6C)cc1c53)C(C)(C)CCC8(C)C)C(C)(C)CC4(C)C)C(C)(C)CCC2(C)C]

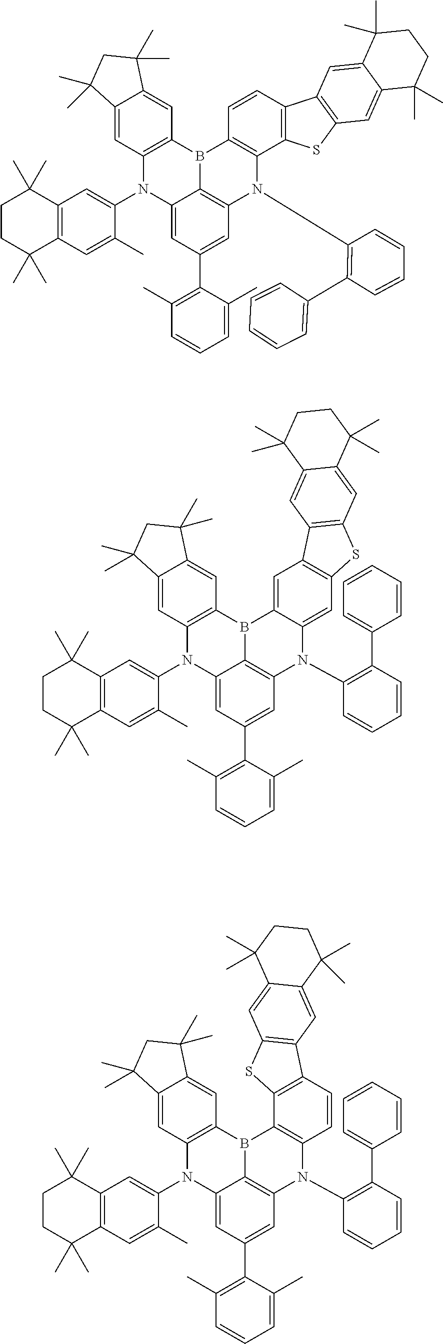 [SMILES: Cc1cc2c(cc1N1c3cc4c(cc3B3c5ccc6c(sc7cc8c(cc76)C(C)(C)CCC8(C)C)c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)sc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(sc6cc7c(cc65)C(C)(C)CCC7(C)C)c13)C(C)(C)CC4(C)C)C(C)(C)CCC2(C)C]

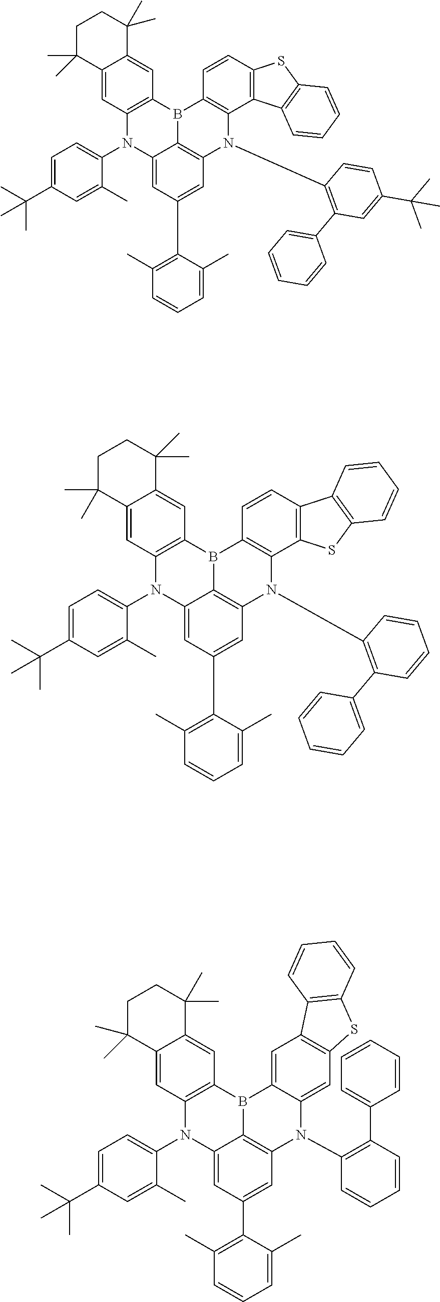

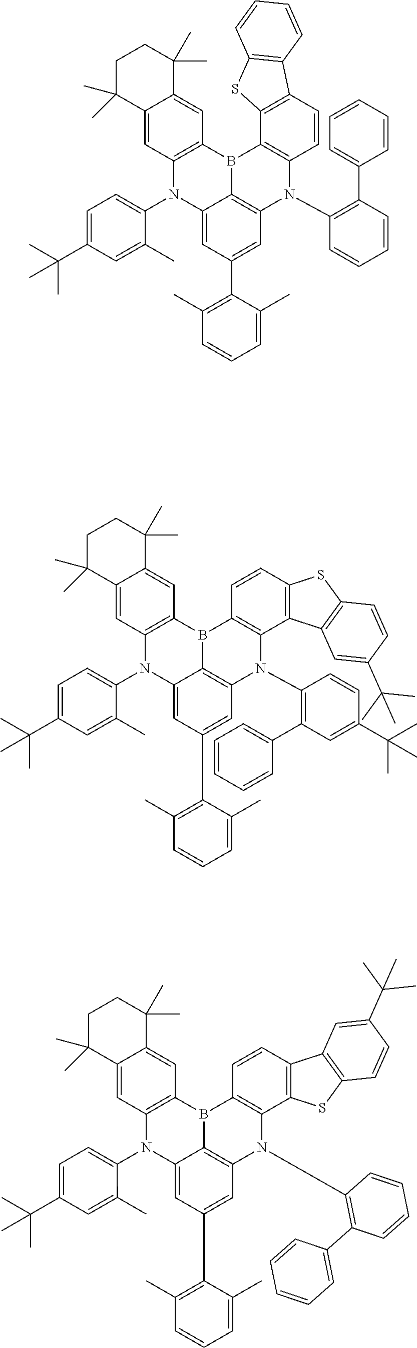

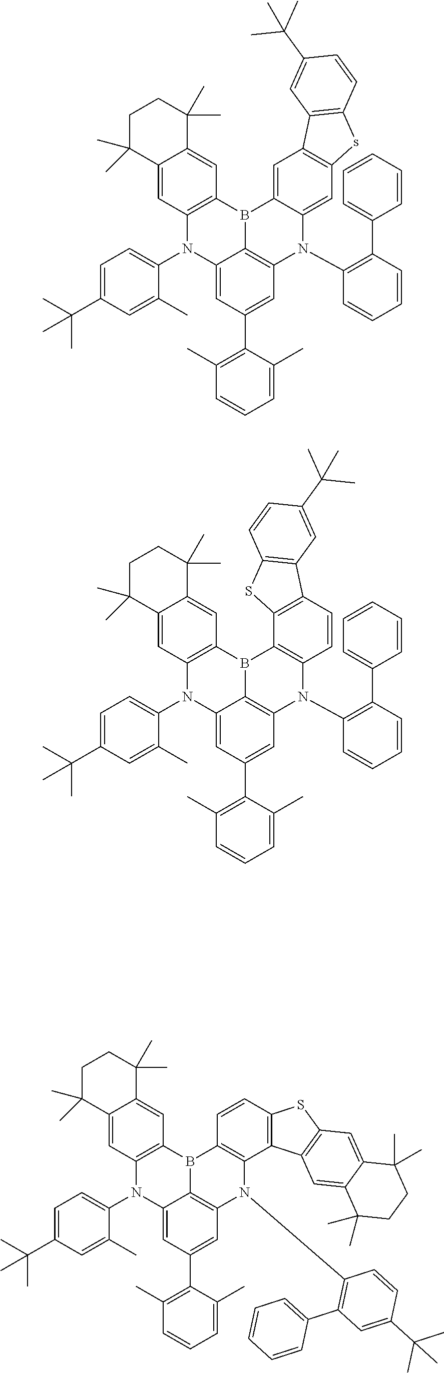

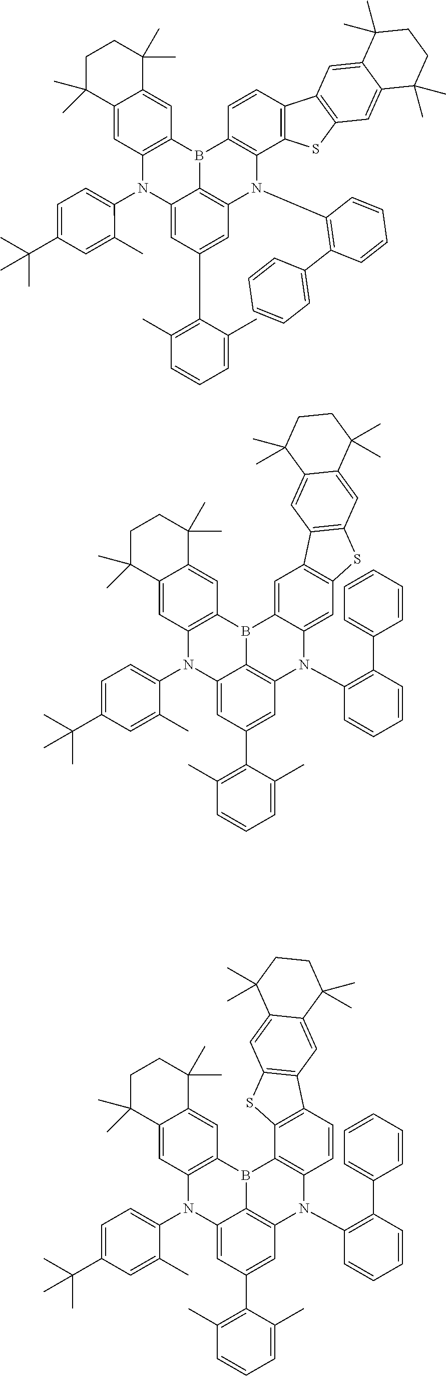

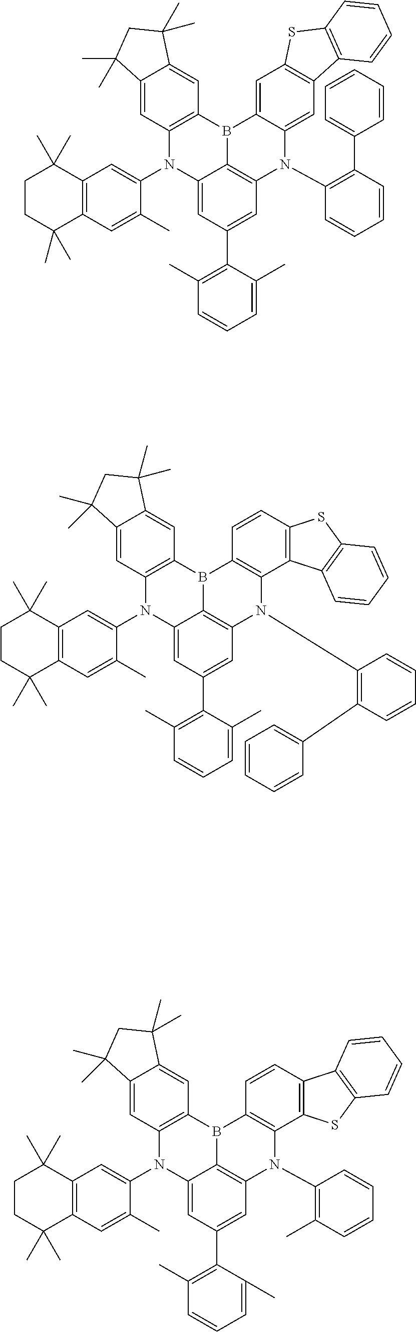 [SMILES: Cc1cc2c(cc1N1c3cc4c(cc3B3c5cc6sc7ccccc7c6cc5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5C)c5cc(-c6c(C)cccc6C)cc1c53)C(C)(C)CC4(C)C)C(C)(C)CCC2(C)C]

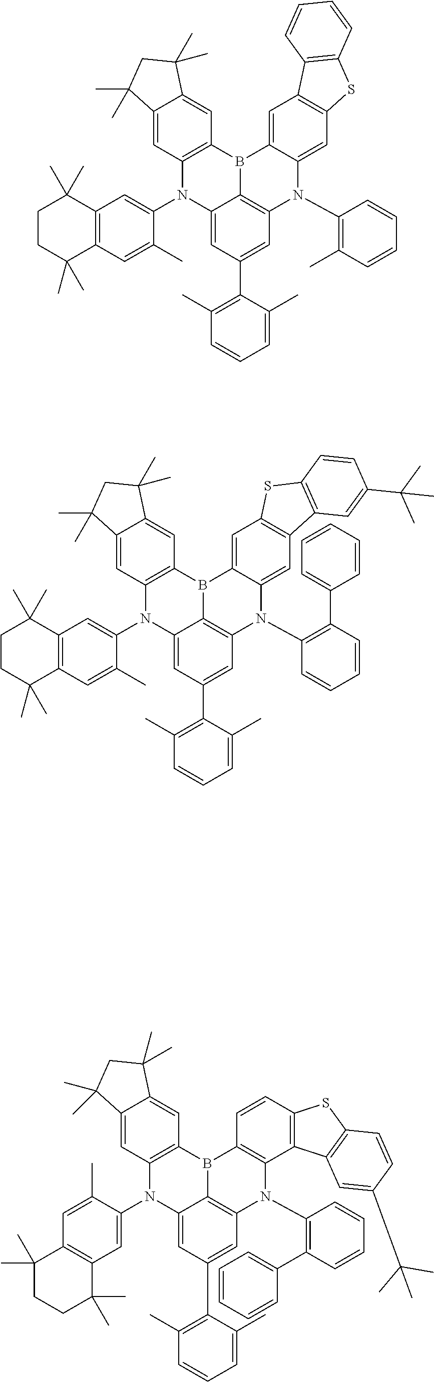

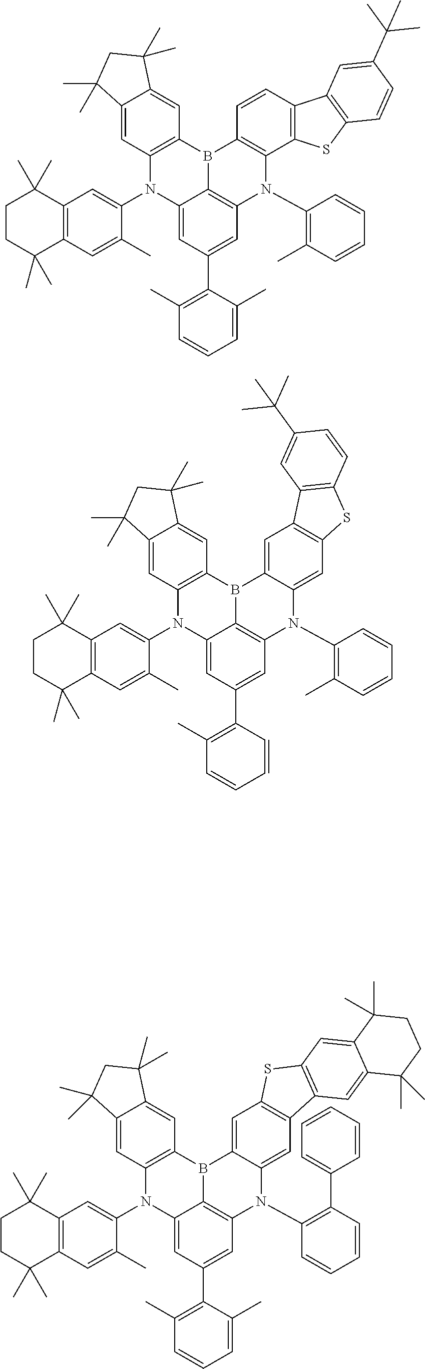

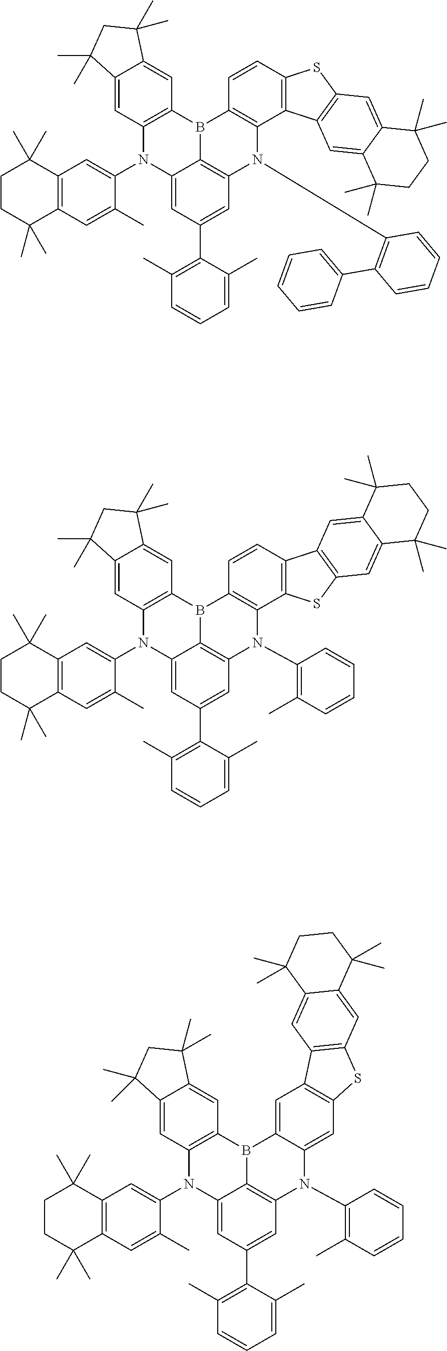 [SMILES: Cc1cc2c(cc1N1c3cc4c(cc3B3c5ccc6sc7cc8c(cc7c6c5N(c5ccccc5-c5ccccc5)c5cc(-c6c(C)cccc6C)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(-c6c(C)cccc6C)cc1c53)C(C)(C)CC4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(-c6c(C)cccc6C)cc1c32)C(C)(C)CC4(C)C)C(C)(C)CCC5(C)C]

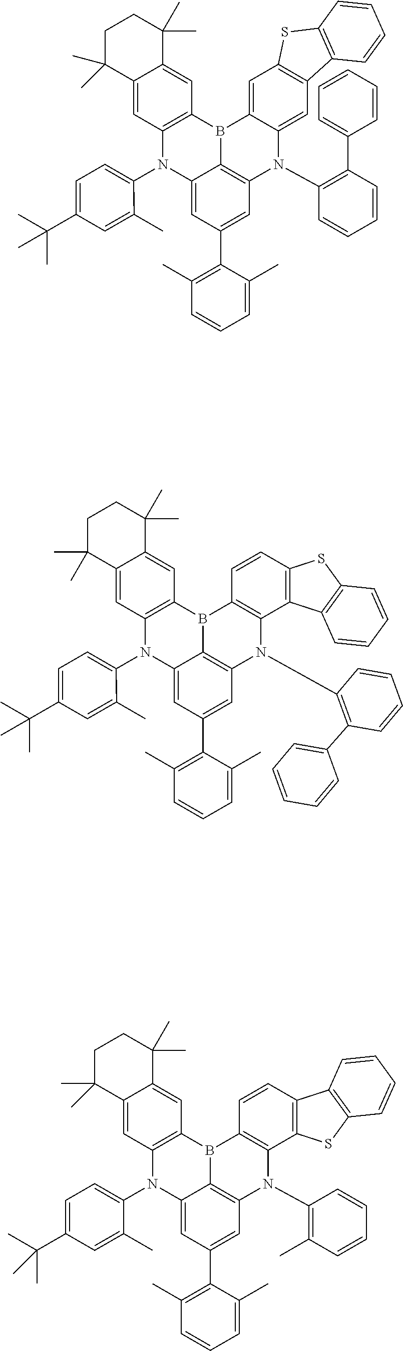 [SMILES: Cc1cc(C(C)(C)C)ccc1N1c2cc3c(cc2B2c4cc5sc6ccccc6c5cc4N(c4ccccc4-c4ccccc4)c4cc(-c5c(C)cccc5C)cc1c42)C(C)(C)CCC3(C)C ; Cc1cc(C(C)(C)C)ccc1N1c2cc3c(cc2B2c4ccc5sc6ccccc6c5c4N(c4ccccc4-c4ccccc4)c4cc(-c5c(C)cccc5C)cc1c42)C(C)(C)CCC3(C)C ; Cc1cc(C(C)(C)C)ccc1N1c2cc3c(cc2B2c4ccc5c(sc6ccccc65)c4N(c4ccccc4C)c4cc(-c5c(C)cccc5C)cc1c42)C(C)(C)CCC3(C)C]

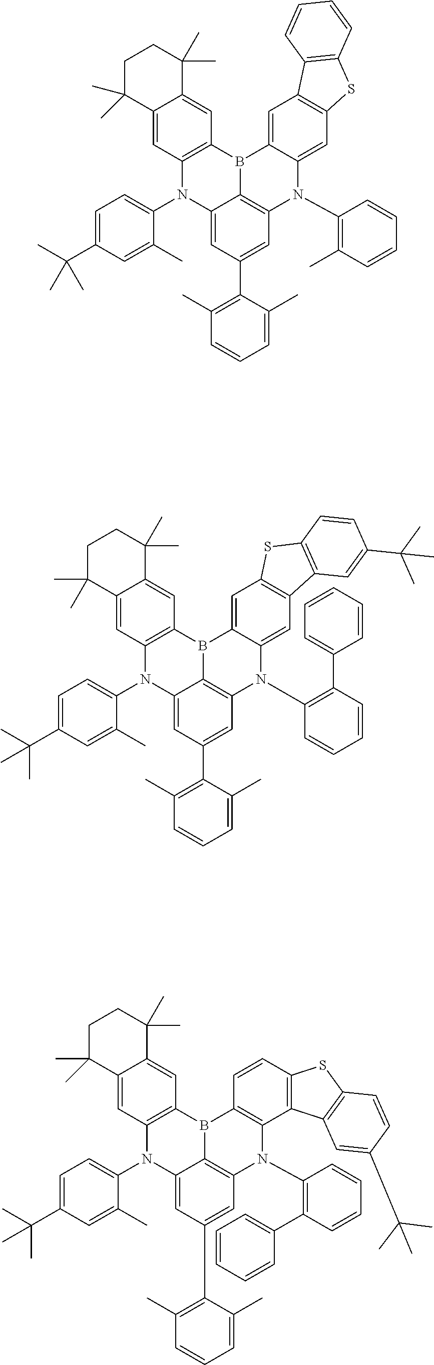

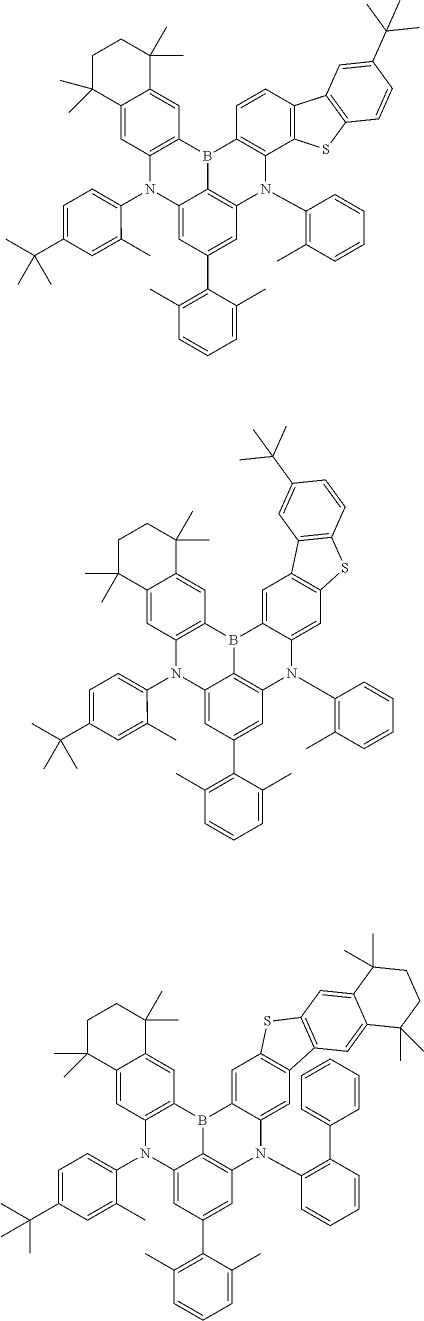

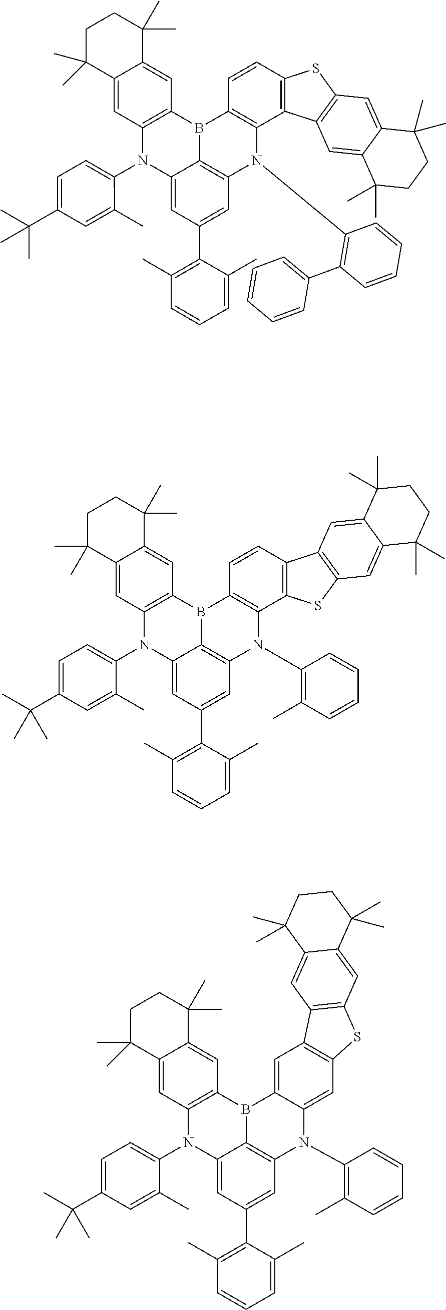

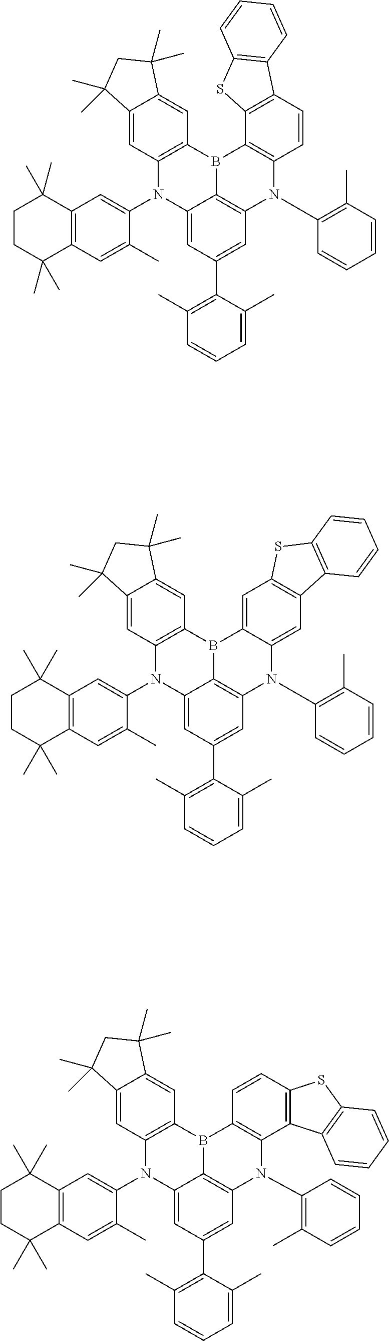 [SMILES: Cc1cc2c(cc1N1c3cc4c(cc3B3c5c1cc(-c1c(C)cccc1C)cc5N(c1ccccc1C)c1ccc5c(sc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)sc1ccccc13 ; Cc1cc2c(cc1N1c3cc4c(cc3B3c5ccc6sc7ccccc7c6c5N(c5ccccc5C)c5cc(-c6c(C)cccc6C)cc1c53)C(C)(C)CC4(C)C)C(C)(C)CCC2(C)C]

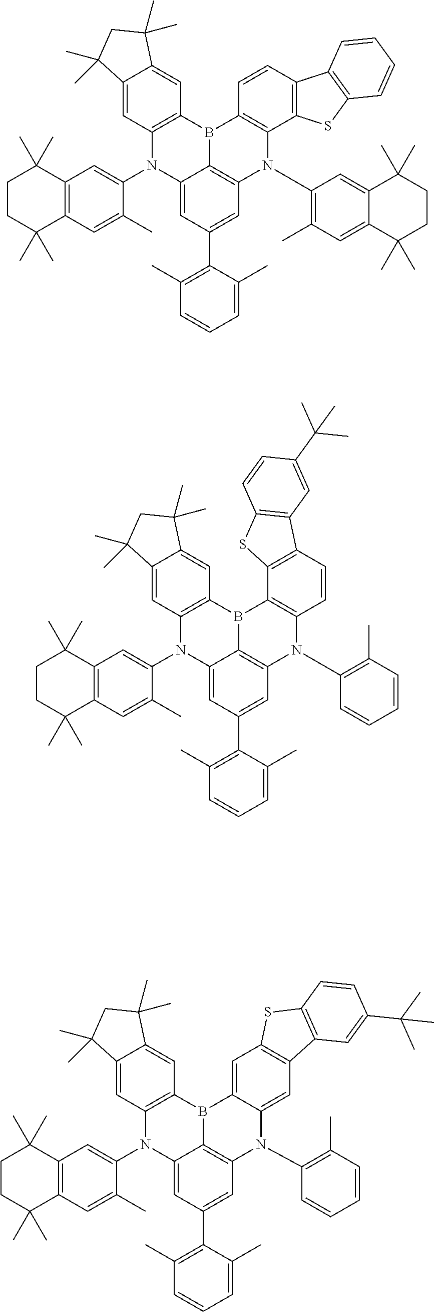 [SMILES: Cc1cc2c(cc1N1c3cc4c(cc3B3c5ccc6c(sc7ccccc76)c5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(sc6ccc(C(C)(C)C)cc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)sc1ccc(C(C)(C)C)cc13]

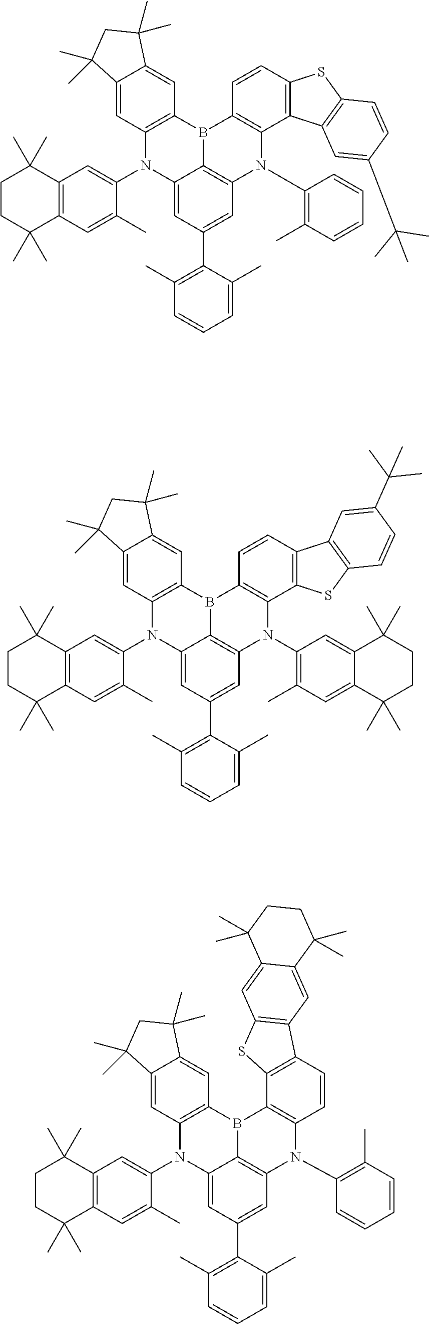 [SMILES: Cc1cc2c(cc1N1c3cc4c(cc3B3c5ccc6sc7ccc(C(C)(C)C)cc7c6c5N(c5ccccc5C)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(sc6cc7c(cc65)C(C)(C)CCC7(C)C)c13)C(C)(C)CC4(C)C)C(C)(C)CCC2(C)C]

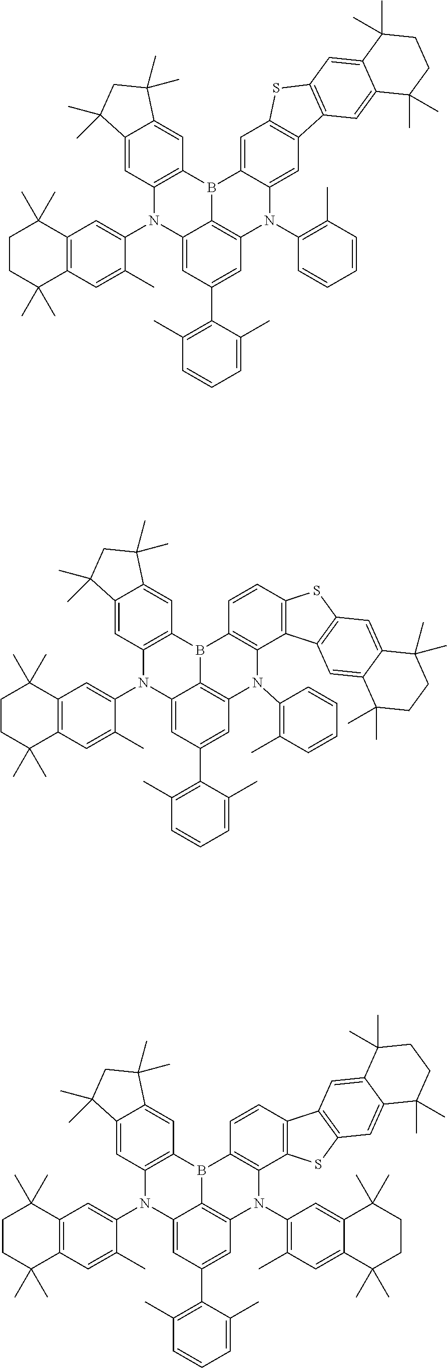 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(-c6c(C)cccc6C)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(-c6c(C)cccc6C)cc1c53)C(C)(C)CC4(C)C)C(C)(C)CCC2(C)C]

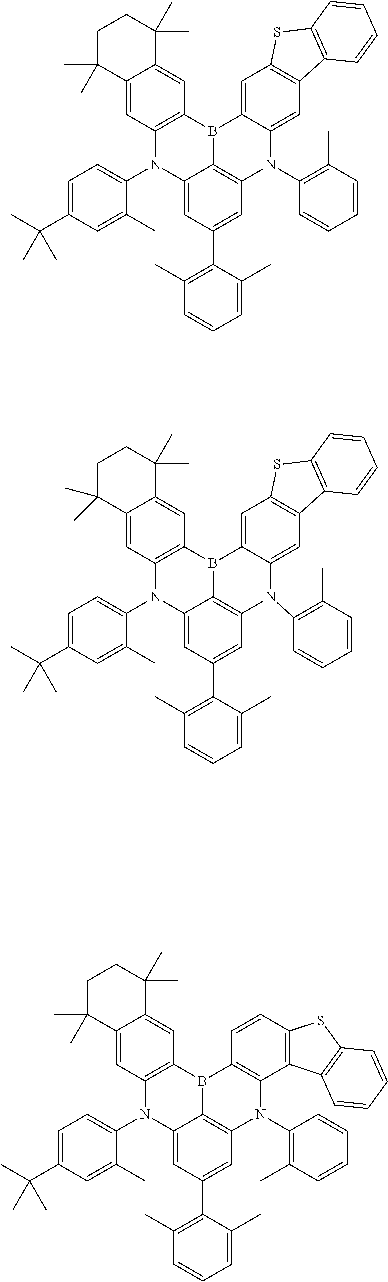 [SMILES: Cc1cc(C(C)(C)C)ccc1N1c2cc3c(cc2B2c4cc5sc6ccccc6c5cc4N(c4ccccc4C)c4cc(-c5c(C)cccc5C)cc1c42)C(C)(C)CCC3(C)C ; Cc1cc(C(C)(C)C)ccc1N1c2cc3c(cc2B2c4cc5sc6ccccc6c5cc4N(c4ccccc4C)c4cc(-c5c(C)cccc5C)cc1c42)C(C)(C)CCC3(C)C ; Cc1cc(C(C)(C)C)ccc1N1c2cc3c(cc2B2c4ccc5sc6ccccc6c5c4N(c4ccccc4C)c4cc(-c5c(C)cccc5C)cc1c42)C(C)(C)CCC3(C)C]

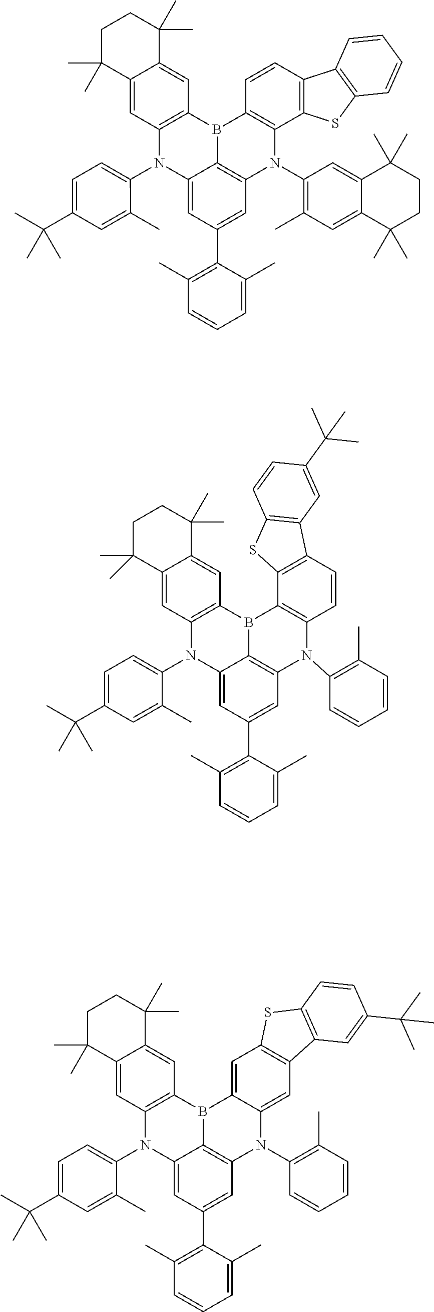 [SMILES: Cc1cc(C(C)(C)C)ccc1N1c2cc3c(cc2B2c4ccc5c(sc6ccccc65)c4N(c4cc5c(cc4C)C(C)(C)CCC5(C)C)c4cc(-c5c(C)cccc5C)cc1c42)C(C)(C)CCC3(C)C ; Cc1cc(C(C)(C)C)ccc1N1c2cc3c(cc2B2c4c1cc(-c1c(C)cccc1C)cc4N(c1ccccc1C)c1ccc4c(sc5ccc(C(C)(C)C)cc54)c12)C(C)(C)CCC3(C)C ; Cc1cc(C(C)(C)C)ccc1N1c2cc3c(cc2B2c4cc5sc6ccc(C(C)(C)C)cc6c5cc4N(c4ccccc4C)c4cc(-c5c(C)cccc5C)cc1c42)C(C)(C)CCC3(C)C]

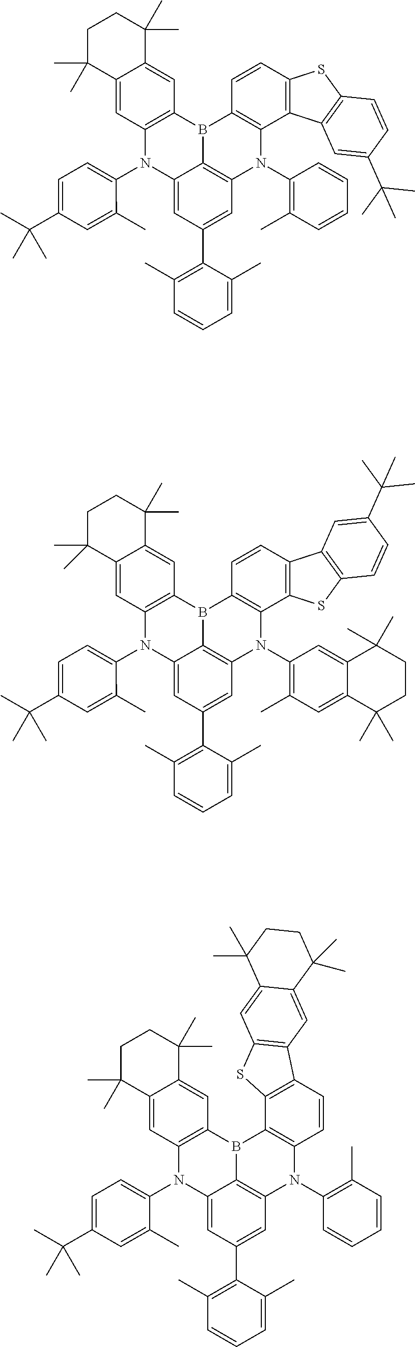

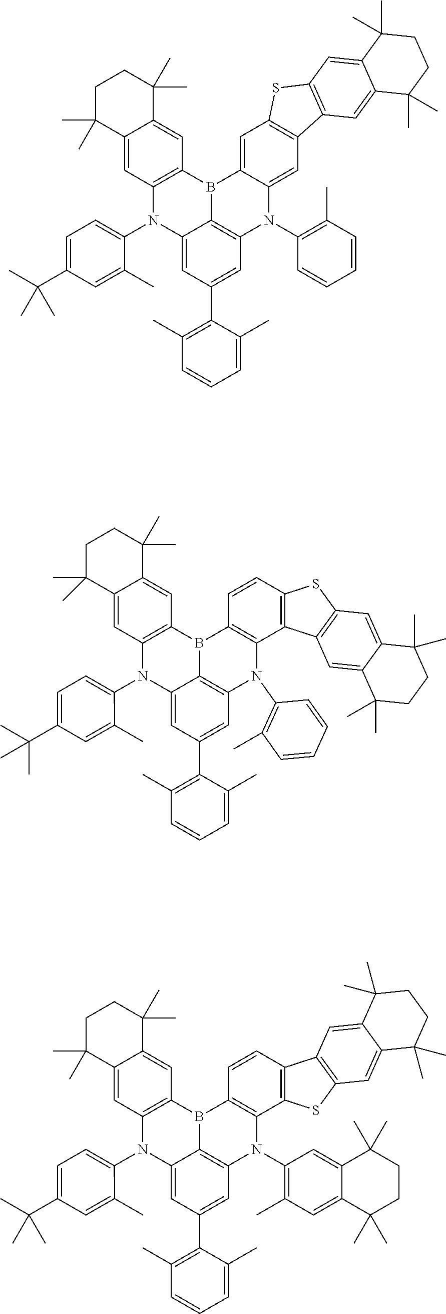

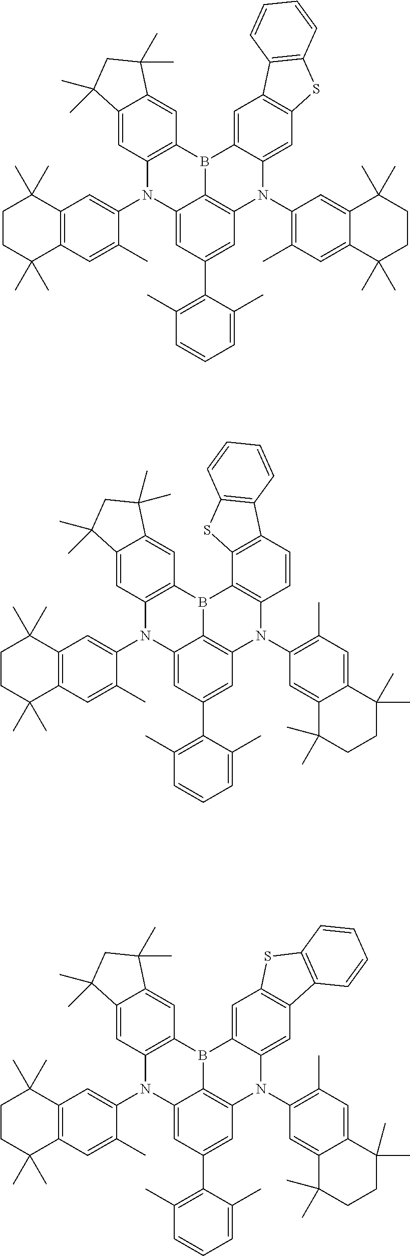 [SMILES: Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)sc1ccccc16)C(C)(C)CC4(C)C)C(C)(C)CCC2(C)C ; Cc1cc2c(cc1N1c3cc4c(cc3B3c5c1cc(-c1c(C)cccc1C)cc5N(c1cc5c(cc1C)C(C)(C)CCC5(C)C)c1ccc5c(sc6ccccc65)c13)C(C)(C)CC4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(-c6c(C)cccc6C)cc1c53)C(C)(C)CC4(C)C)C(C)(C)CCC2(C)C]

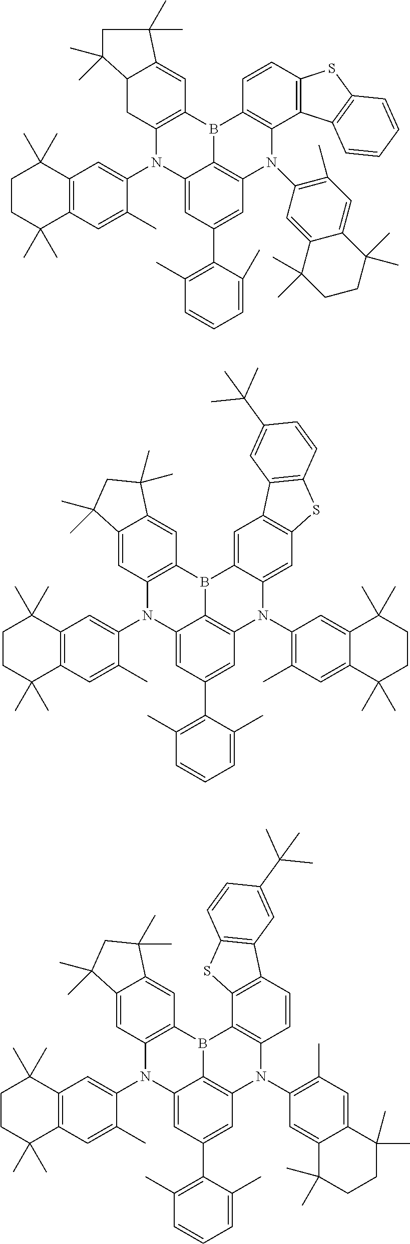

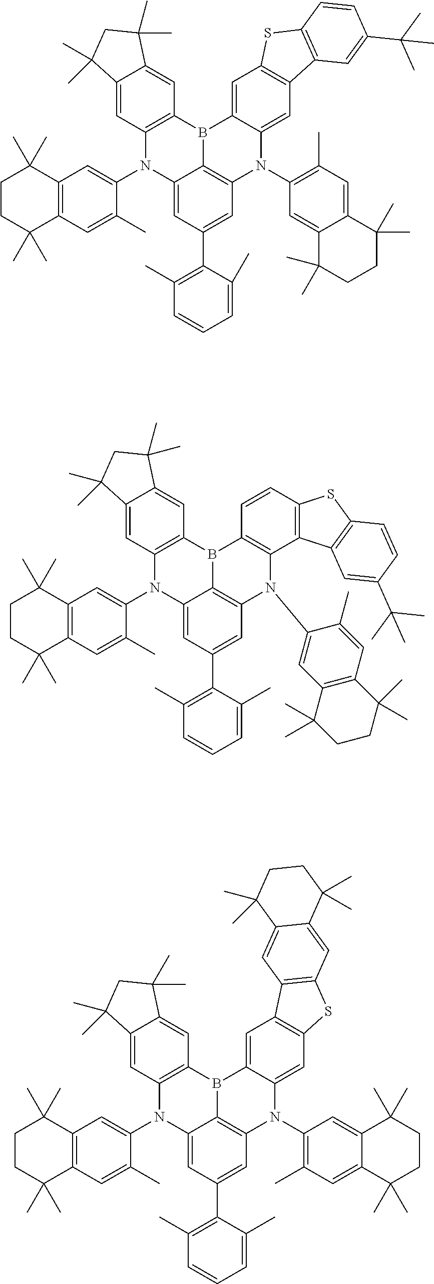 [SMILES: Cc1cc2c(cc1N1c3cc4c(cc3B3c5cc6sc7ccc(C(C)(C)C)cc7c6cc5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)sc1cc3c(cc16)C(C)(C)CCC3(C)C)C(C)(C)CC4(C)C)C(C)(C)CCC2(C)C]

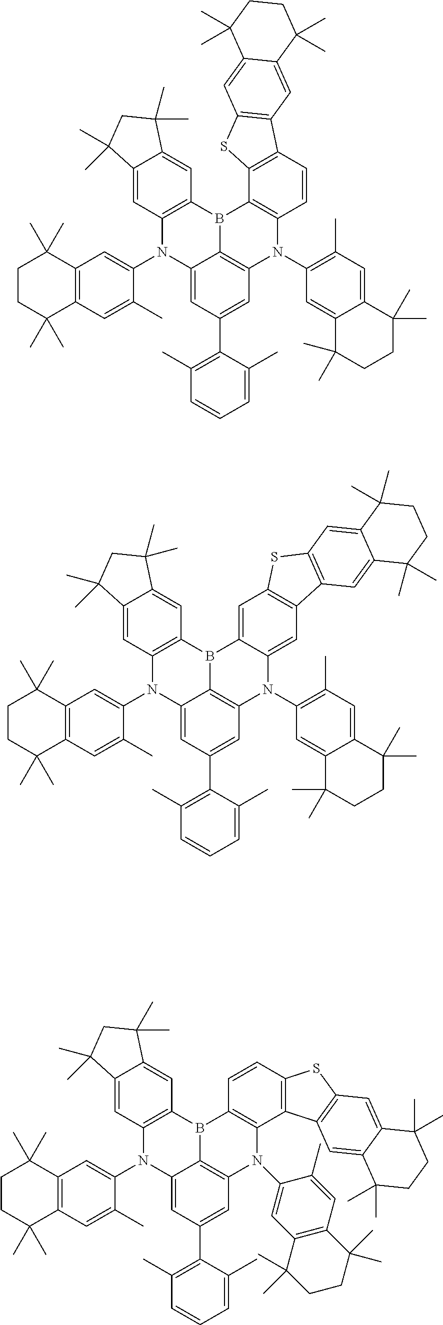 [SMILES: Cc1cc2c(cc1N1c3cc4c(cc3B3c5c1cc(-c1c(C)cccc1C)cc5N(c1cc5c(cc1C)C(C)(C)CCC5(C)C)c1ccc5c(sc6cc7c(cc65)C(C)(C)CCC7(C)C)c13)C(C)(C)CC4(C)C)C(C)(C)CCC2(C)C ; Cc1cc2c(cc1N1c3cc4c(cc3B3c5cc6sc7cc8c(cc7c6cc5N(c5cc6c(cc5C)C(C)(C)CCC6(C)C)c5cc(-c6c(C)cccc6C)cc1c53)C(C)(C)CCC8(C)C)C(C)(C)CC4(C)C)C(C)(C)CCC2(C)C ; Cc1cc2c(cc1N1c3cc4c(cc3B3c5ccc6sc7cc8c(cc7c6c5N(c5cc6c(cc5C)C(C)(C)CCC6(C)C)c5cc(-c6c(C)cccc6C)cc1c53)C(C)(C)CCC8(C)C)C(C)(C)CC4(C)C)C(C)(C)CCC2(C)C]

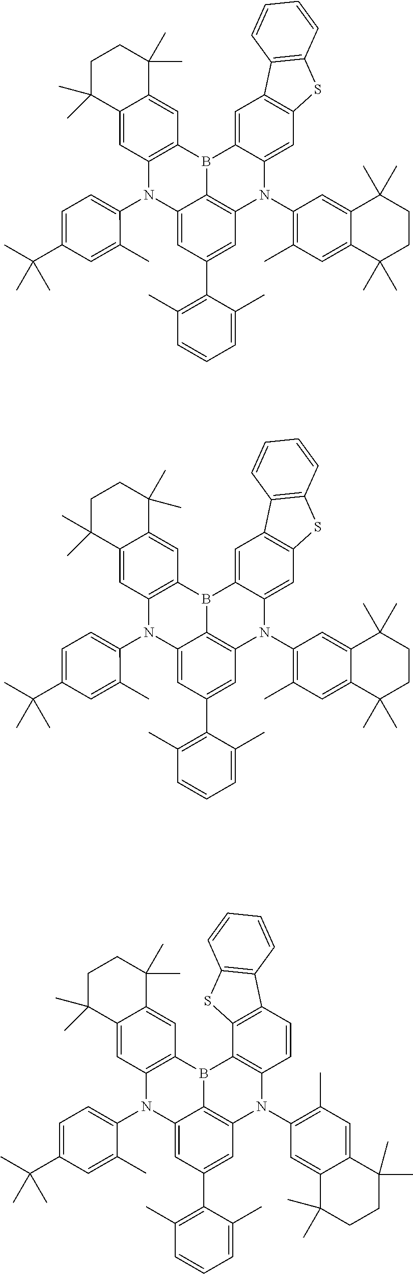 [SMILES: Cc1cc(C(C)(C)C)ccc1N1c2cc3c(cc2B2c4cc5c(cc4N(c4cc6c(cc4C)C(C)(C)CCC6(C)C)c4cc(-c6c(C)cccc6C)cc1c42)sc1ccccc15)C(C)(C)CCC3(C)C ; Cc1cc(C(C)(C)C)ccc1N1c2cc3c(cc2B2c4cc5c(cc4N(c4cc6c(cc4C)C(C)(C)CCC6(C)C)c4cc(-c6c(C)cccc6C)cc1c42)sc1ccccc15)C(C)(C)CCC3(C)C ; Cc1cc(C(C)(C)C)ccc1N1c2cc3c(cc2B2c4c1cc(-c1c(C)cccc1C)cc4N(c1cc4c(cc1C)C(C)(C)CCC4(C)C)c1ccc4c(sc5ccccc54)c12)C(C)(C)CCC3(C)C]

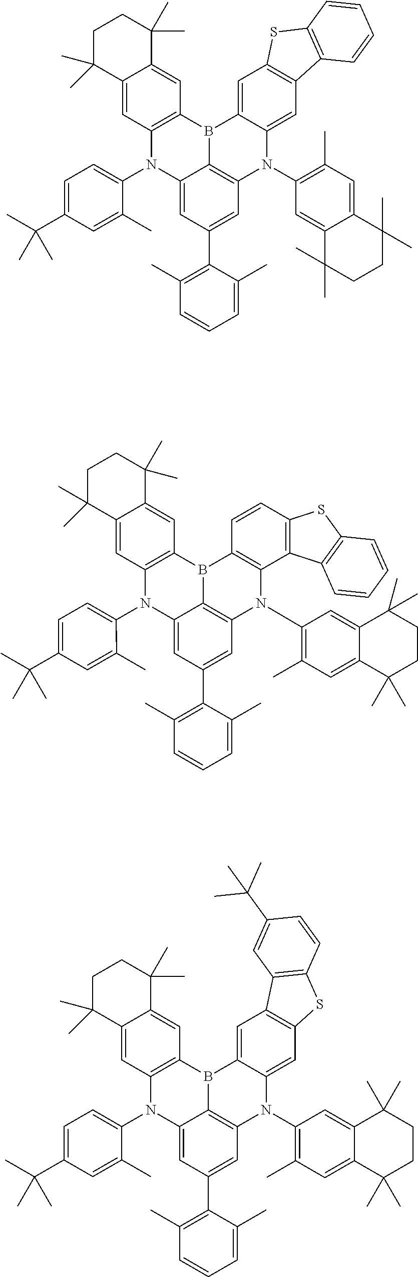

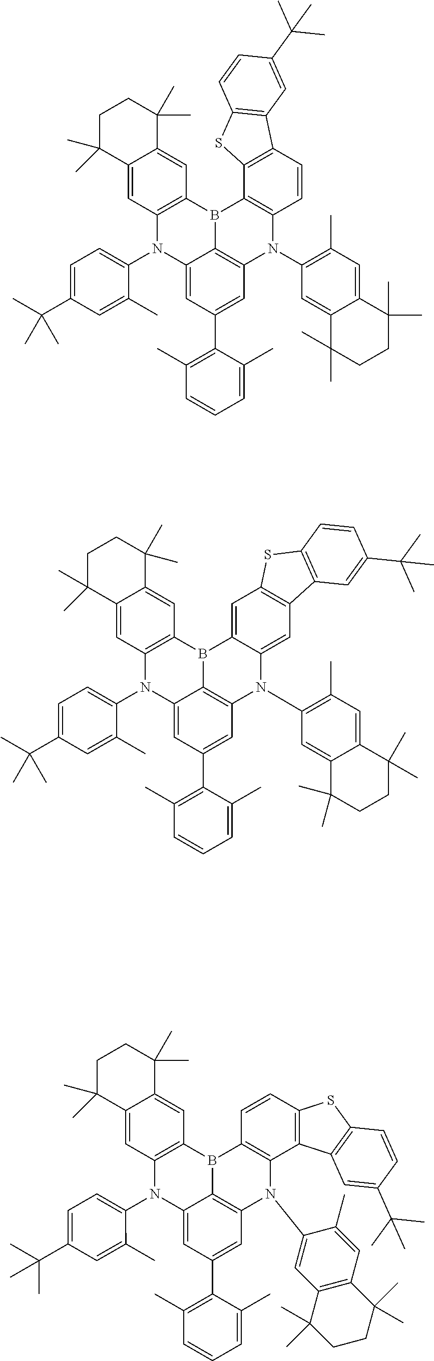

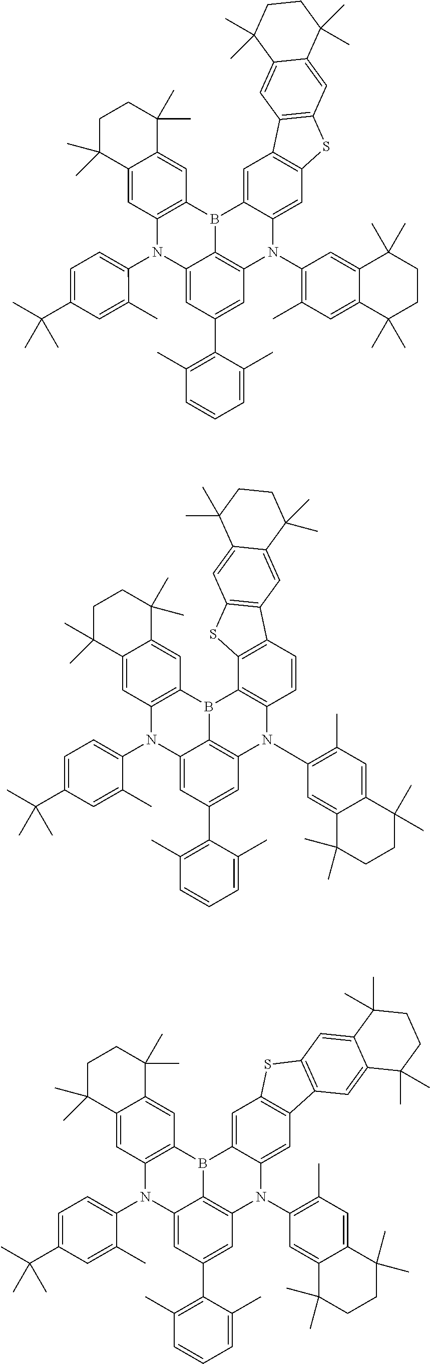

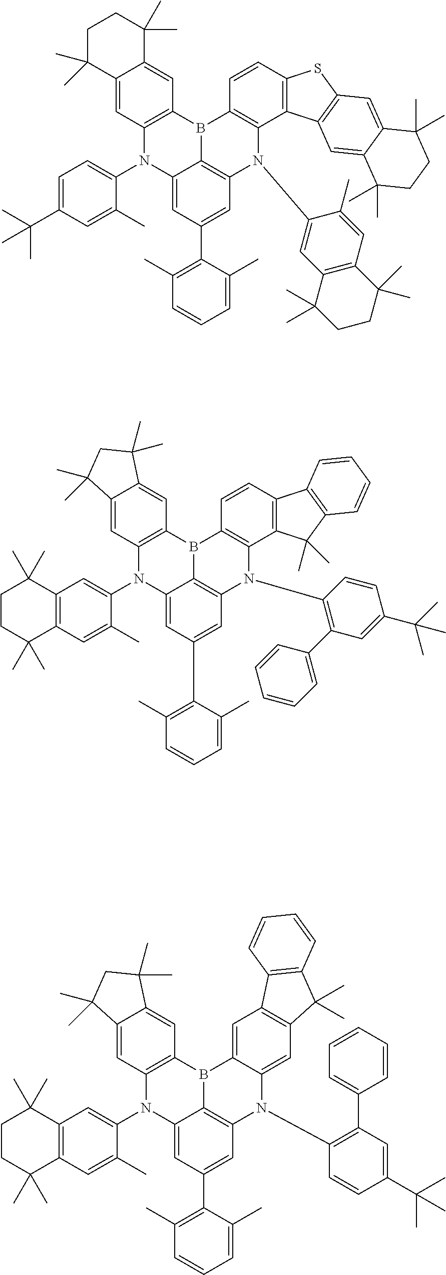 [SMILES: Cc1cc(C(C)(C)C)ccc1N1c2cc3c(cc2B2c4ccc5sc6cc7c(cc6c5c4N(c4cc5c(cc4C)C(C)(C)CCC5(C)C)c4cc(-c5c(C)cccc5C)cc1c42)C(C)(C)CCC7(C)C)C(C)(C)CCC3(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1ccccc1-6)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1ccccc1-6)C(C)(C)CC4(C)C)C(C)(C)CCC2(C)C]

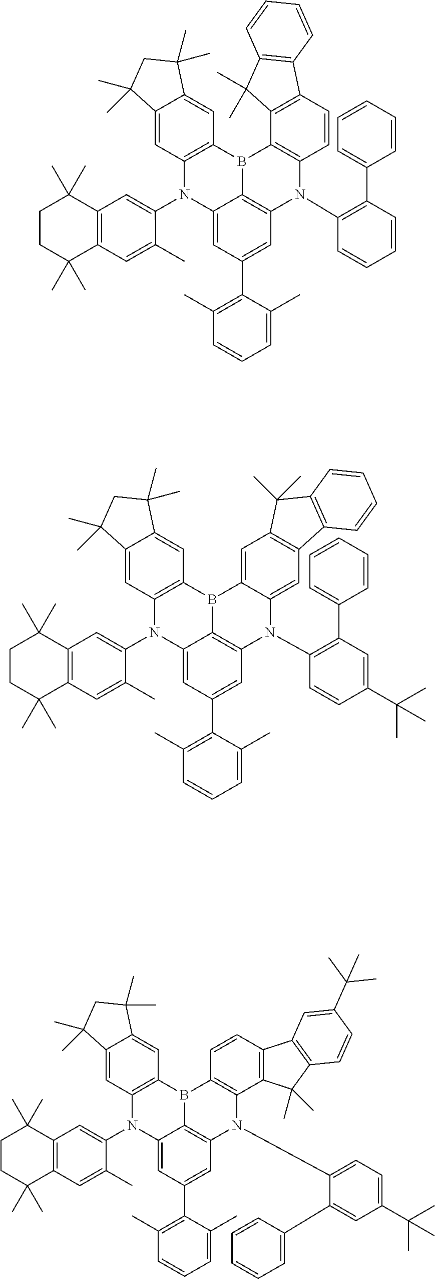 [SMILES: Cc1cc2c(cc1N1c3cc4c(cc3B3c5c1cc(-c1c(C)cccc1C)cc5N(c1ccccc1-c1ccccc1)c1ccc5c(c13)C(C)(C)c1ccccc1-5)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1ccc(C(C)(C)C)cc1-6)C(C)(C)CC4(C)C)C(C)(C)CCC2(C)C]

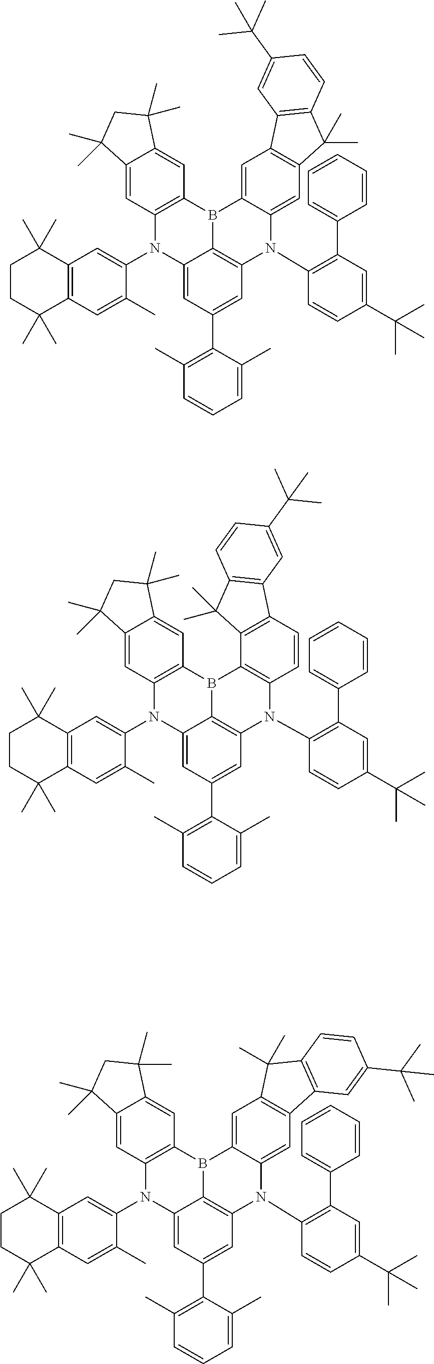 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(c13)C(C)(C)c1ccc(C(C)(C)C)cc1-5)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)-c1cc(C(C)(C)C)ccc1C6(C)C)C(C)(C)CC4(C)C)C(C)(C)CCC2(C)C]

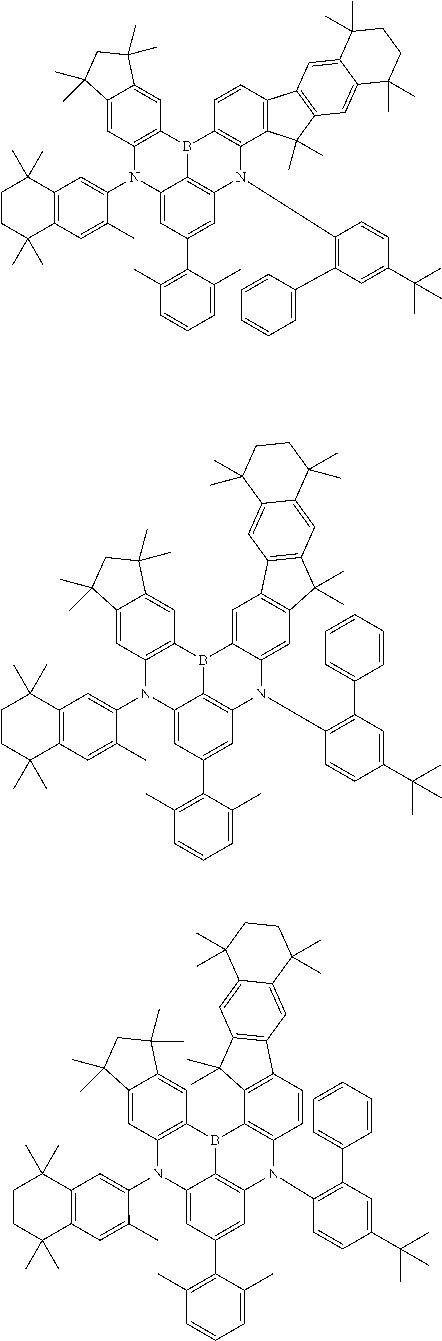 [SMILES: Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(c13)C(C)(C)c1cc3c(cc1-5)C(C)(C)CCC3(C)C)C(C)(C)CC4(C)C)C(C)(C)CCC2(C)C]

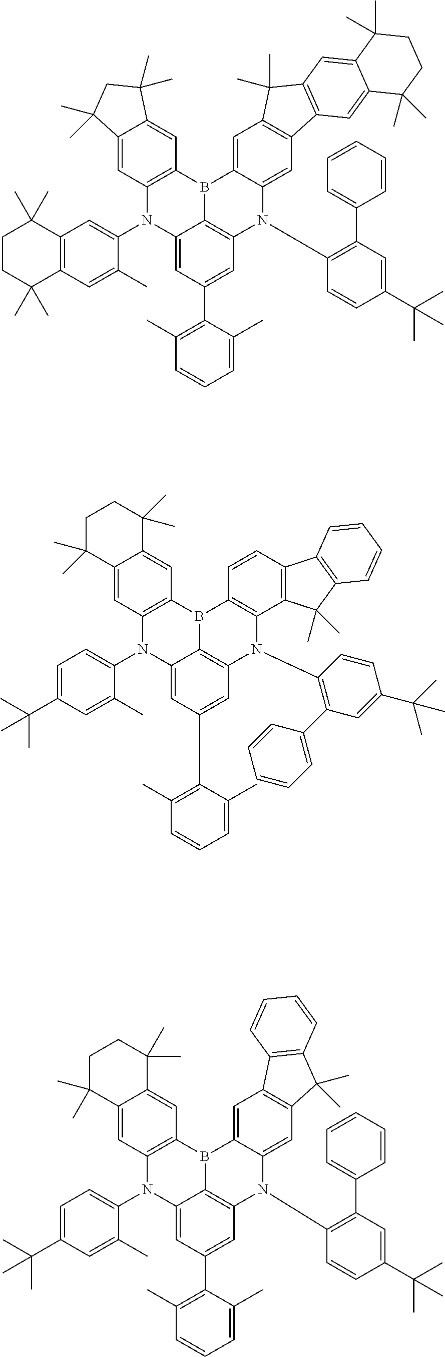

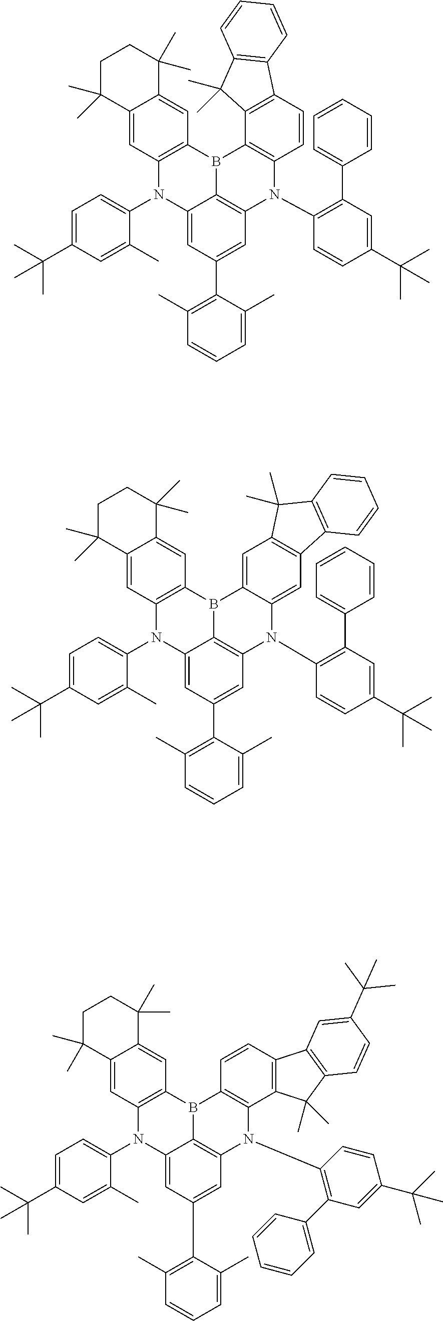

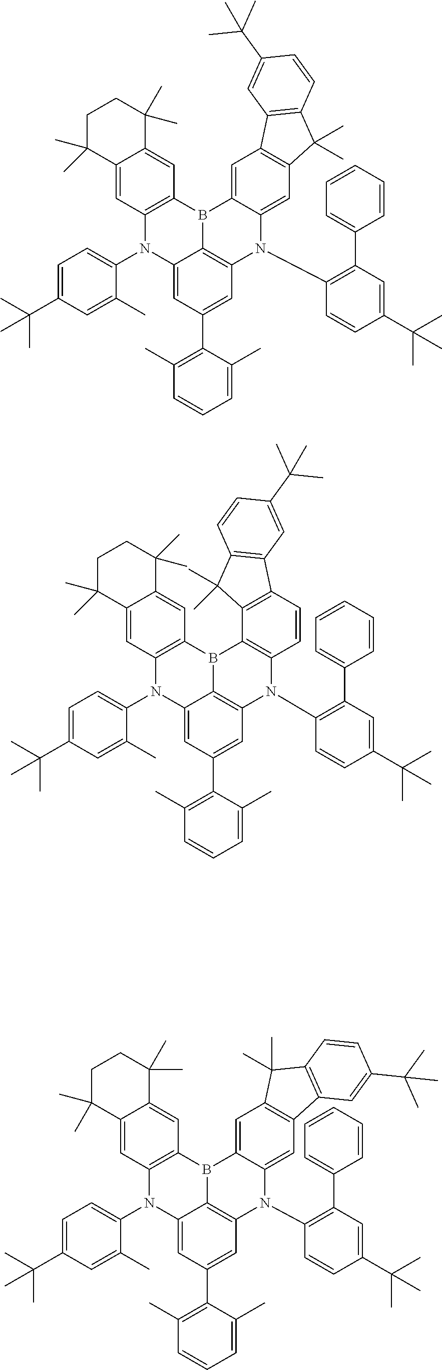

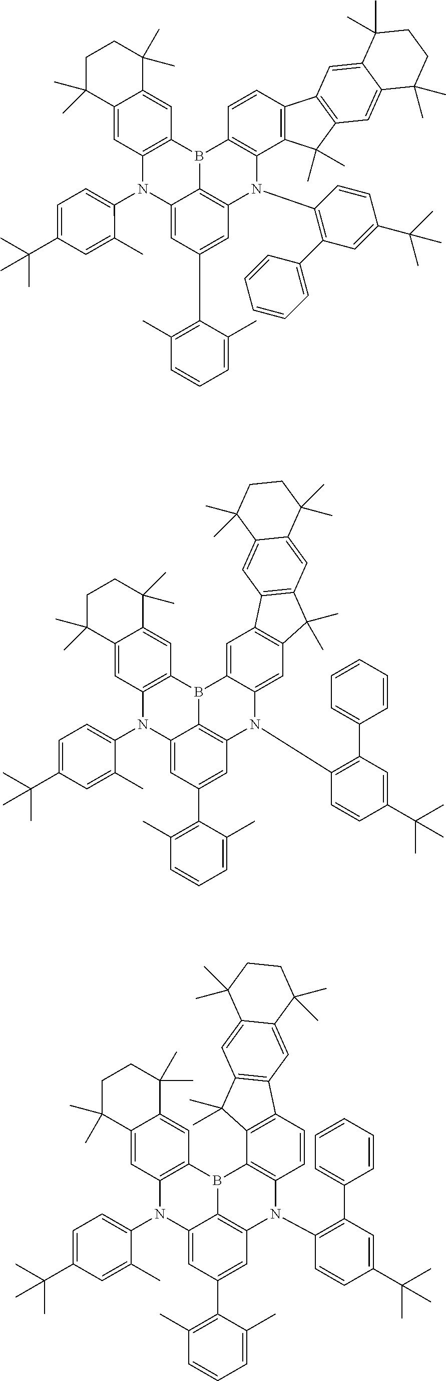

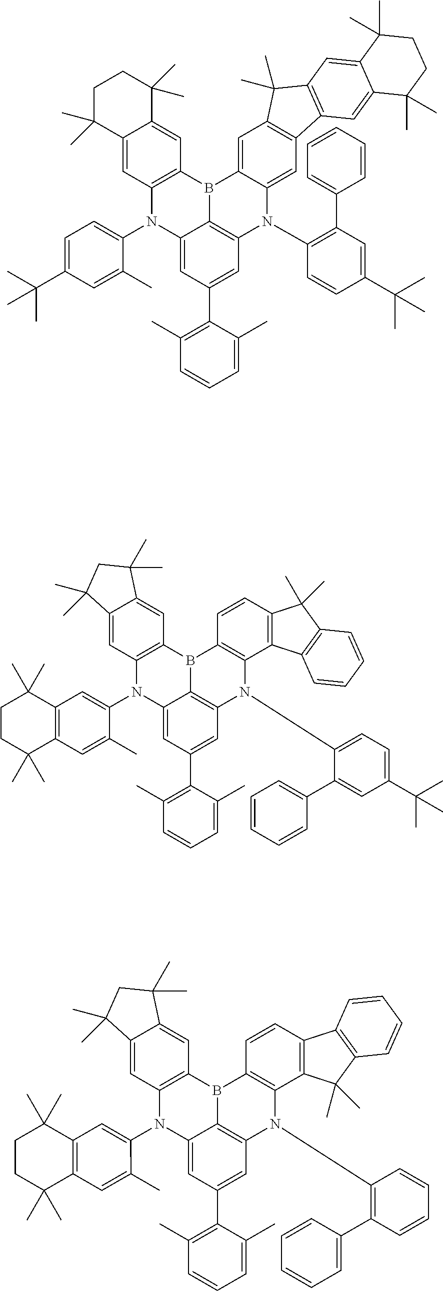 [SMILES: Cc1cc(C(C)(C)C)ccc1N1c2cc3c(cc2B2c4cc5c(cc4N(c4ccc(C(C)(C)C)cc4-c4ccccc4)c4cc(-c6c(C)cccc6C)cc1c42)-c1cc2c(cc1C5(C)C)C(C)(C)CCC2(C)C)C(C)(C)CCC3(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1ccccc1-6)C(C)(C)CC4(C)C)C(C)(C)CCC2(C)C]

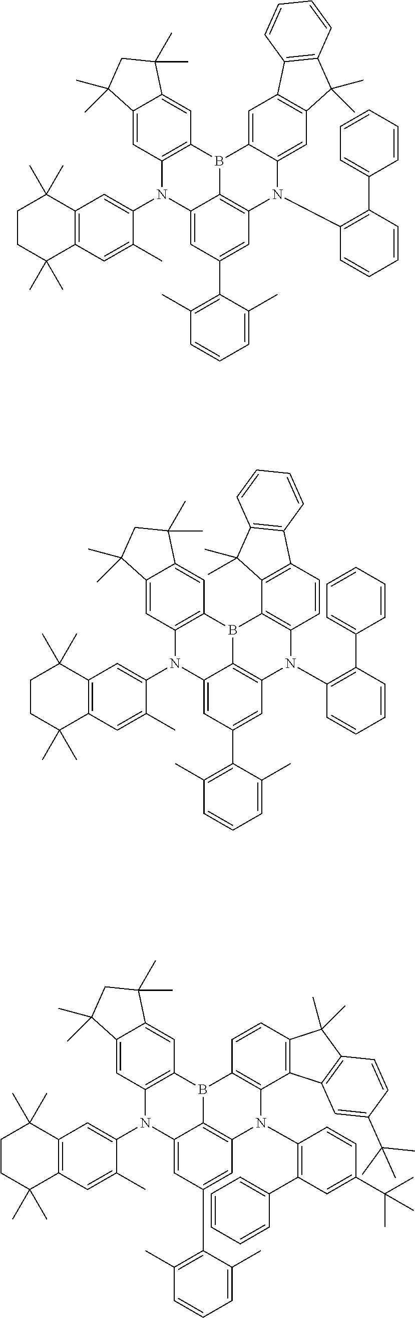 [SMILES: Cc1cc2c(cc1N1c3cc4c(cc3B3c5cc6c(cc5N(c5ccccc5-c5ccccc5)c5cc(-c7c(C)cccc7C)cc1c53)C(C)(C)c1ccccc1-6)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(c13)C(C)(C)c1ccccc1-5)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc(C(C)(C)C)ccc1C6(C)C)C(C)(C)CC4(C)C)C(C)(C)CCC2(C)C]

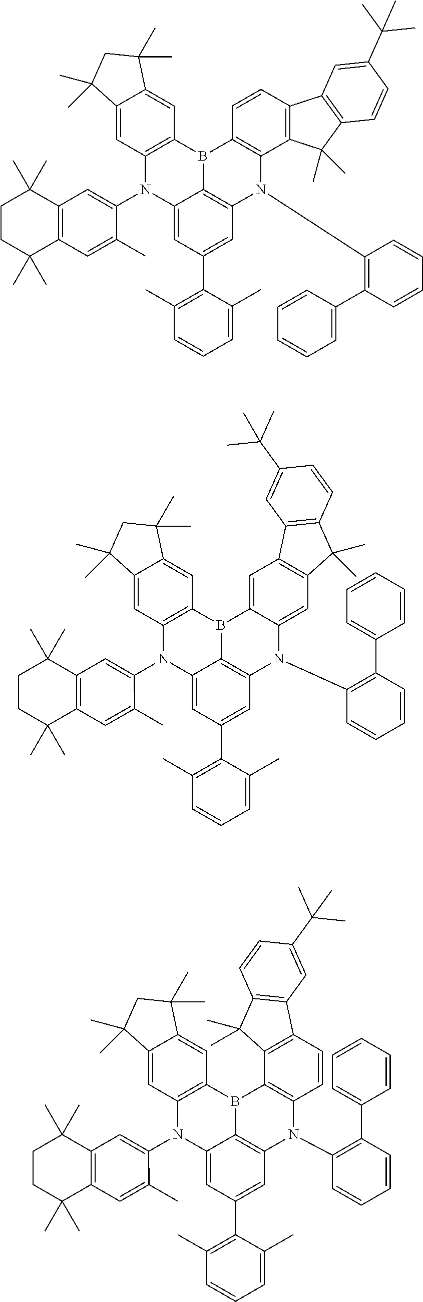 [SMILES: Cc1cc2c(cc1N1c3cc4c(cc3B3c5ccc6c(c5N(c5ccccc5-c5ccccc5)c5cc(-c7c(C)cccc7C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(c13)C(C)(C)c1ccc(C(C)(C)C)cc1-5)C(C)(C)CC4(C)C)C(C)(C)CCC2(C)C]

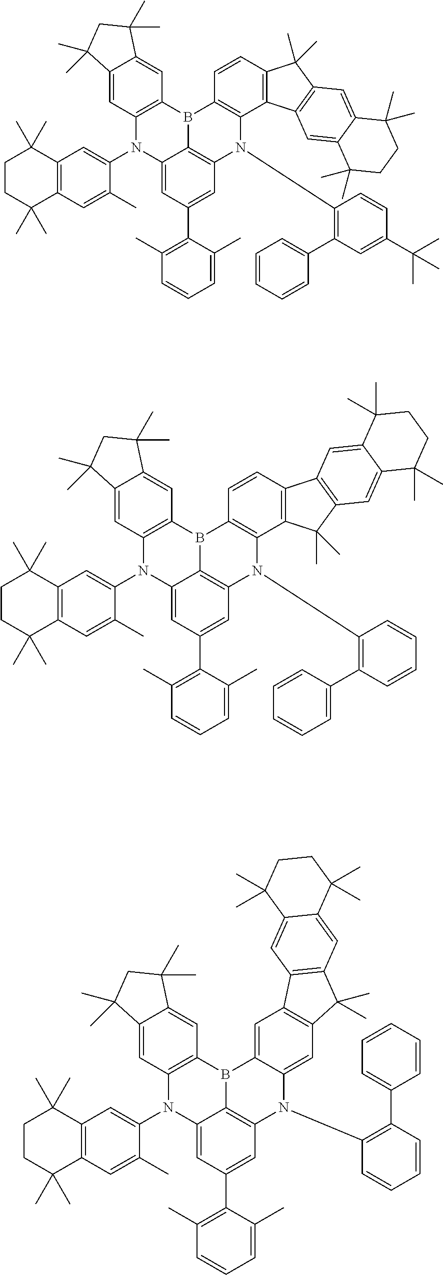 [SMILES: Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)C(C)(C)c1cc3c(cc1-6)C(C)(C)CCC3(C)C)C(C)(C)CC4(C)C)C(C)(C)CCC2(C)C]

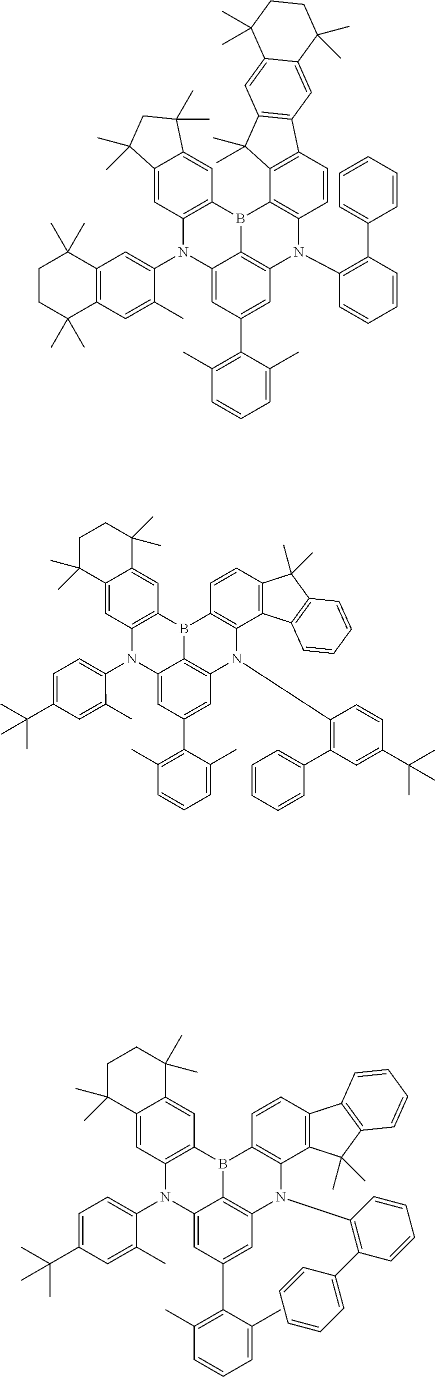

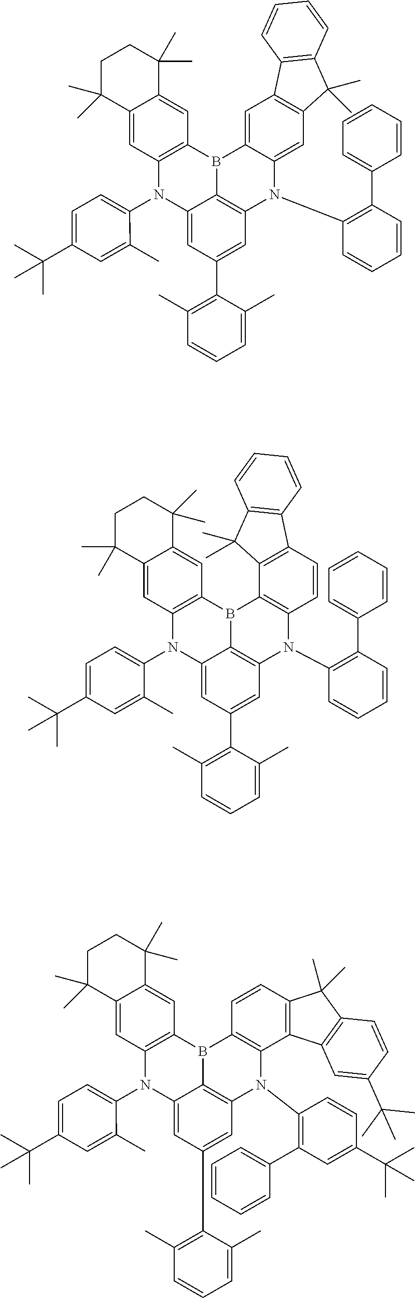 [SMILES: Cc1cc(C(C)(C)C)ccc1N1c2cc3c(cc2B2c4cc5c(cc4N(c4ccccc4-c4ccccc4)c4cc(-c6c(C)cccc6C)cc1c42)C(C)(C)c1ccccc1-5)C(C)(C)CCC3(C)C ; Cc1cc(C(C)(C)C)ccc1N1c2cc3c(cc2B2c4c1cc(-c1c(C)cccc1C)cc4N(c1ccccc1-c1ccccc1)c1ccc4c(c12)C(C)(C)c1ccccc1-4)C(C)(C)CCC3(C)C ; Cc1cc(C(C)(C)C)ccc1N1c2cc3c(cc2B2c4ccc5c(c4N(c4ccc(C(C)(C)C)cc4-c4ccccc4)c4cc(-c6c(C)cccc6C)cc1c42)-c1cc(C(C)(C)C)ccc1C5(C)C)C(C)(C)CCC3(C)C]

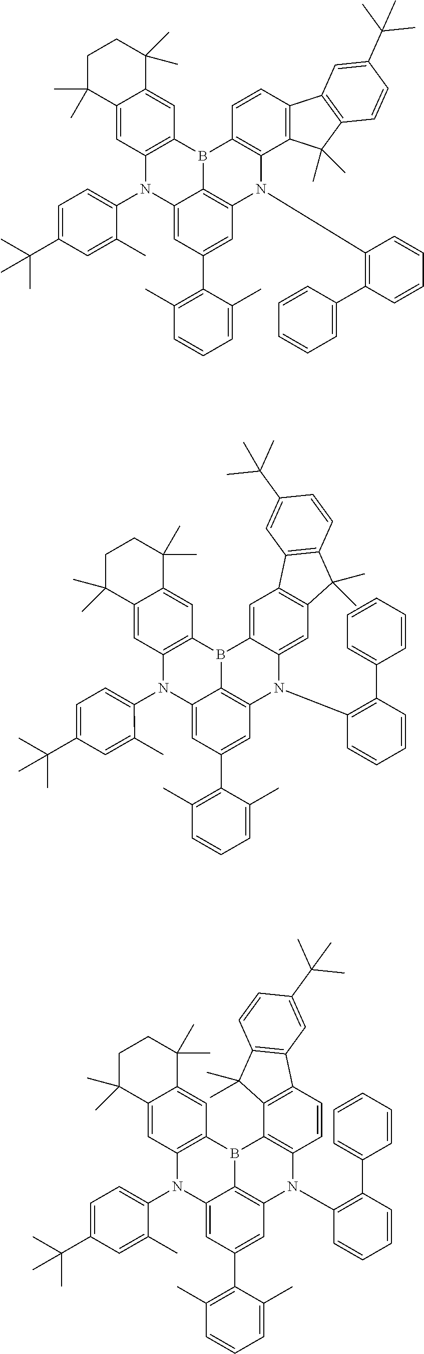 [SMILES: Cc1cc(C(C)(C)C)ccc1N1c2cc3c(cc2B2c4ccc5c(c4N(c4ccccc4-c4ccccc4)c4cc(-c6c(C)cccc6C)cc1c42)C(C)(C)c1ccc(C(C)(C)C)cc1-5)C(C)(C)CCC3(C)C ; Cc1cc(C(C)(C)C)ccc1N1c2cc3c(cc2B2c4cc5c(cc4N(c4ccccc4-c4ccccc4)c4cc(-c6c(C)cccc6C)cc1c42)C(C)(C)c1ccc(C(C)(C)C)cc1-5)C(C)(C)CCC3(C)C ; Cc1cc(C(C)(C)C)ccc1N1c2cc3c(cc2B2c4c1cc(-c1c(C)cccc1C)cc4N(c1ccccc1-c1ccccc1)c1ccc4c(c12)C(C)(C)c1ccc(C(C)(C)C)cc1-4)C(C)(C)CCC3(C)C]

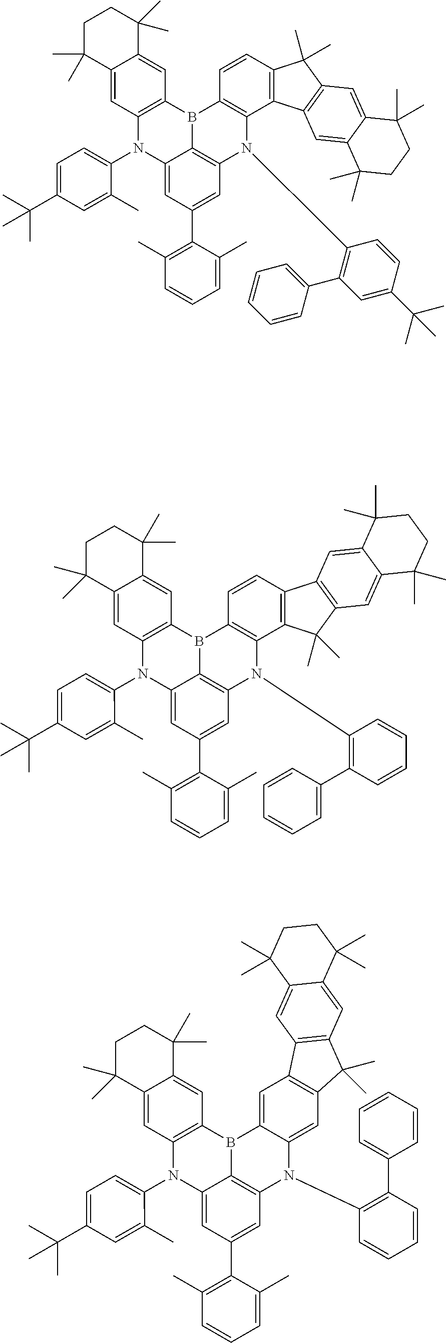

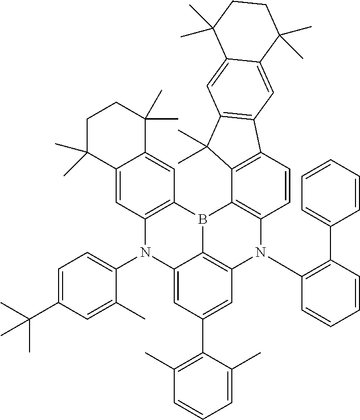 [SMILES: Cc1cc(C(C)(C)C)ccc1N1c2cc3c(cc2B2c4c1cc(-c1c(C)cccc1C)cc4N(c1ccccc1-c1ccccc1)c1ccc4c(c12)C(C)(C)c1cc2c(cc1-4)C(C)(C)CCC2(C)C)C(C)(C)CCC3(C)C]

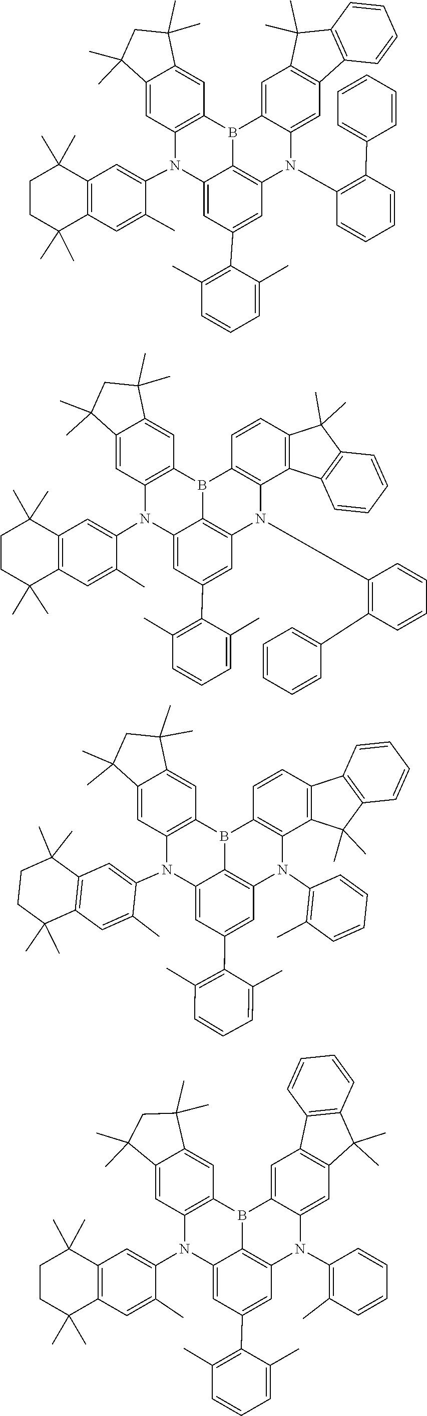

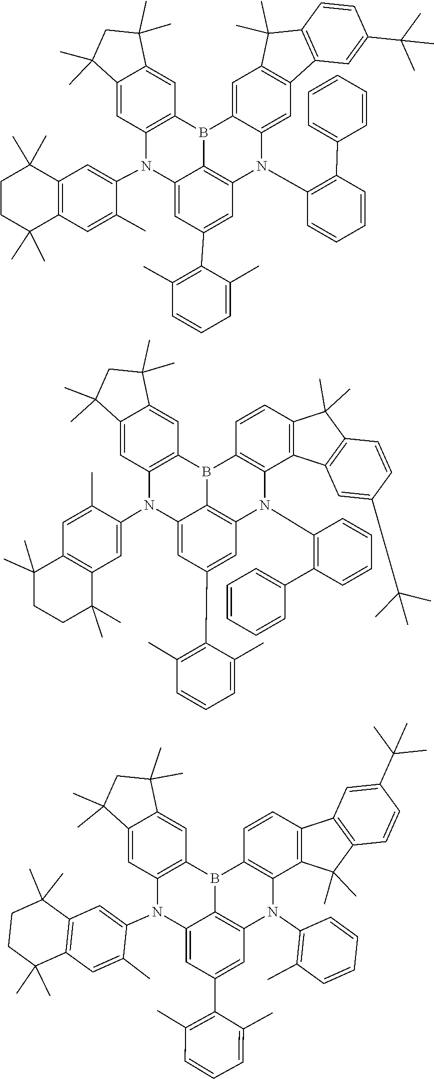

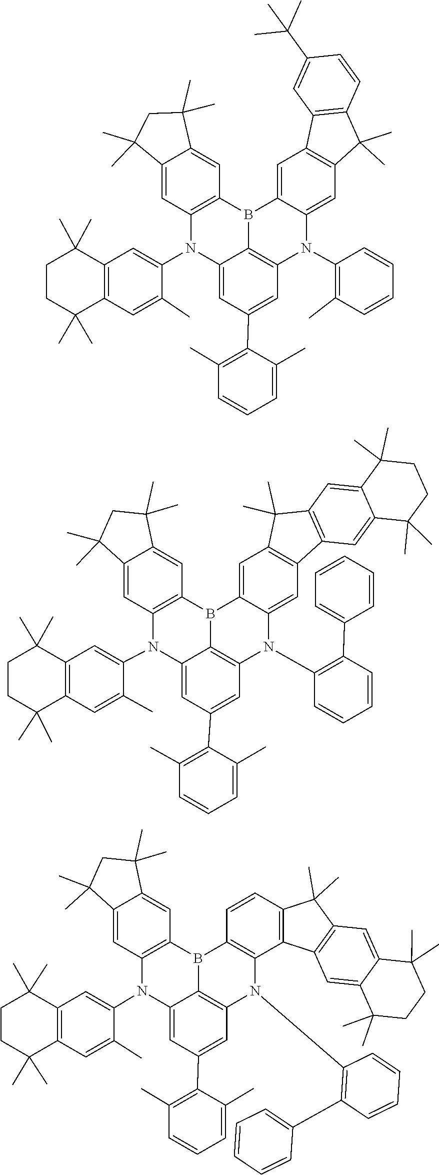 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)-c1cc(C(C)(C)C)ccc1C3(C)C ; Cc1cc2c(cc1N1c3cc4c(cc3B3c5cc6c(cc5N(c5ccccc5-c5ccccc5)c5cc(-c7c(C)cccc7C)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)-c1cc3c(cc1C6(C)C)C(C)(C)CCC3(C)C)C(C)(C)CC4(C)C)C(C)(C)CCC2(C)C]

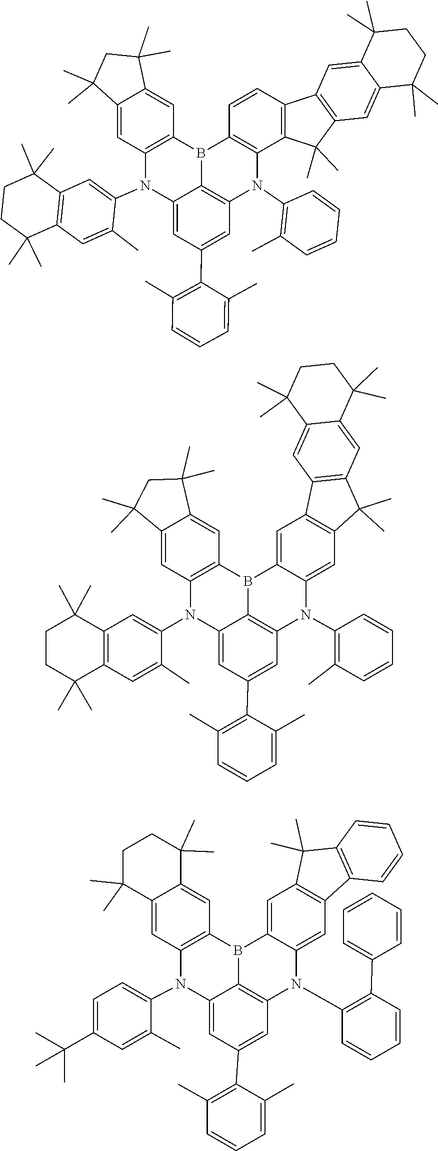

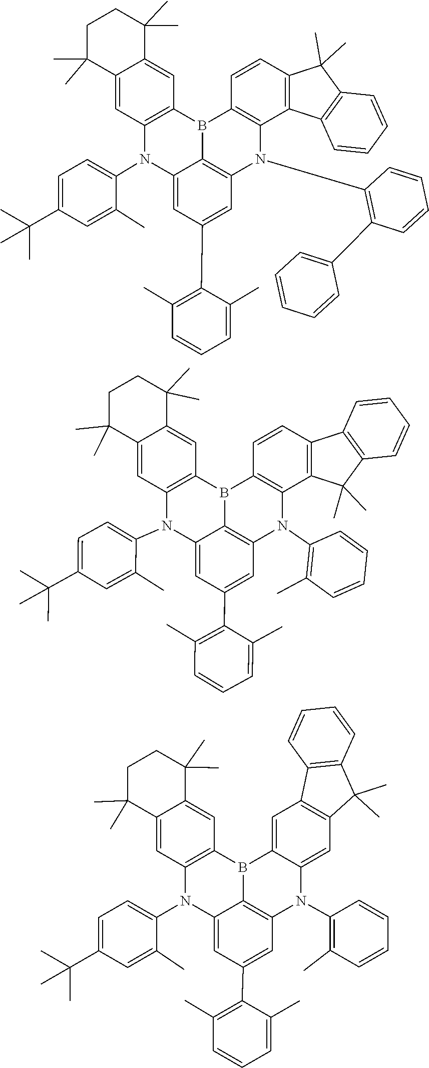

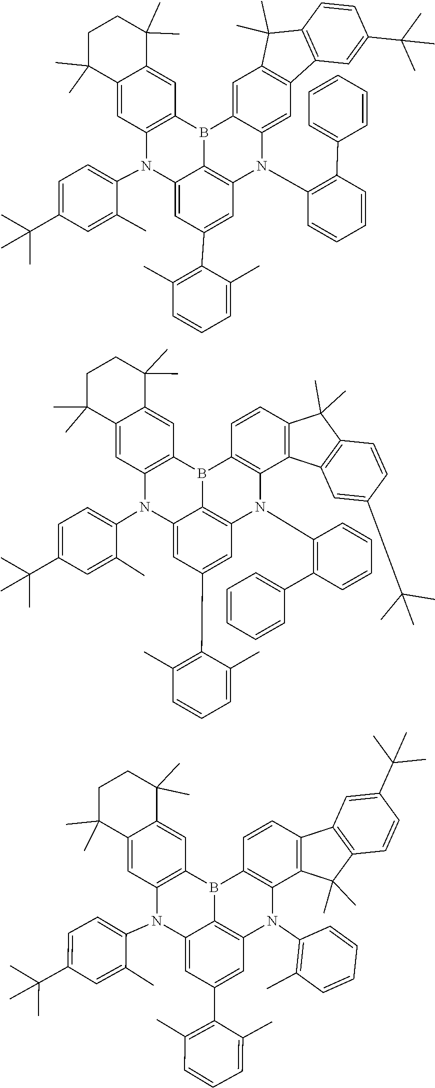

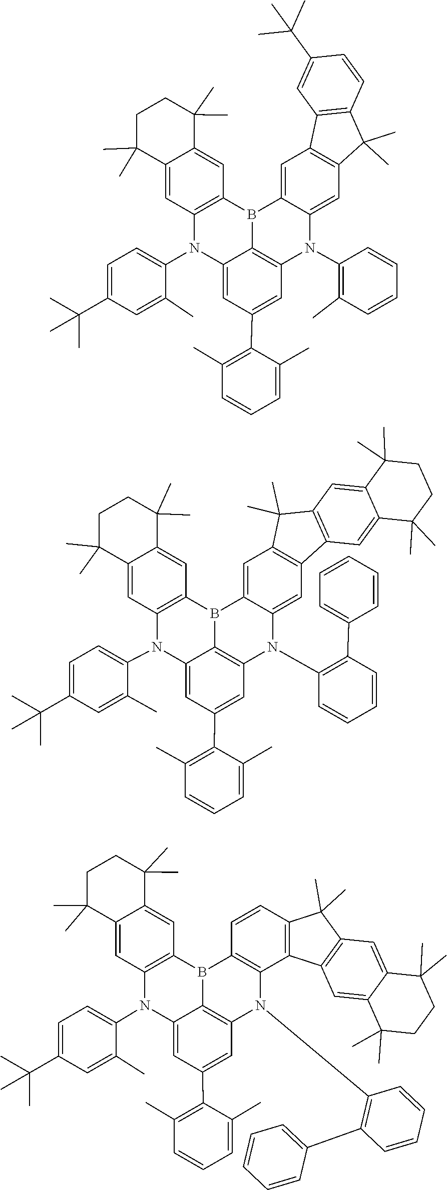

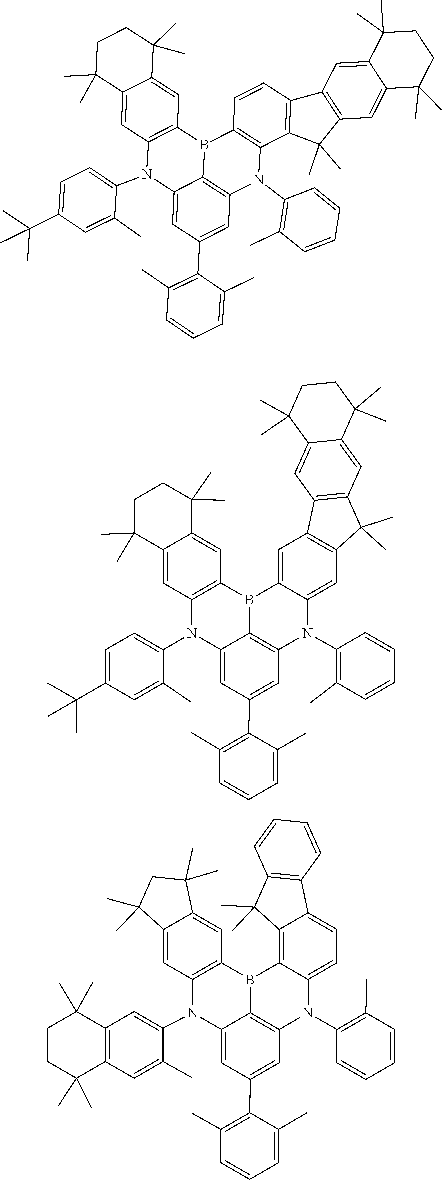

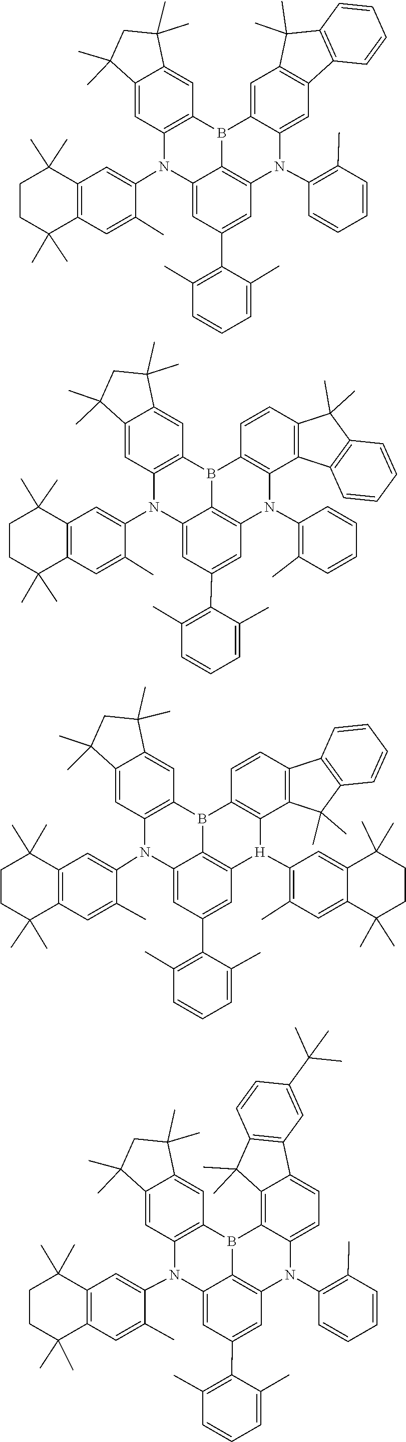

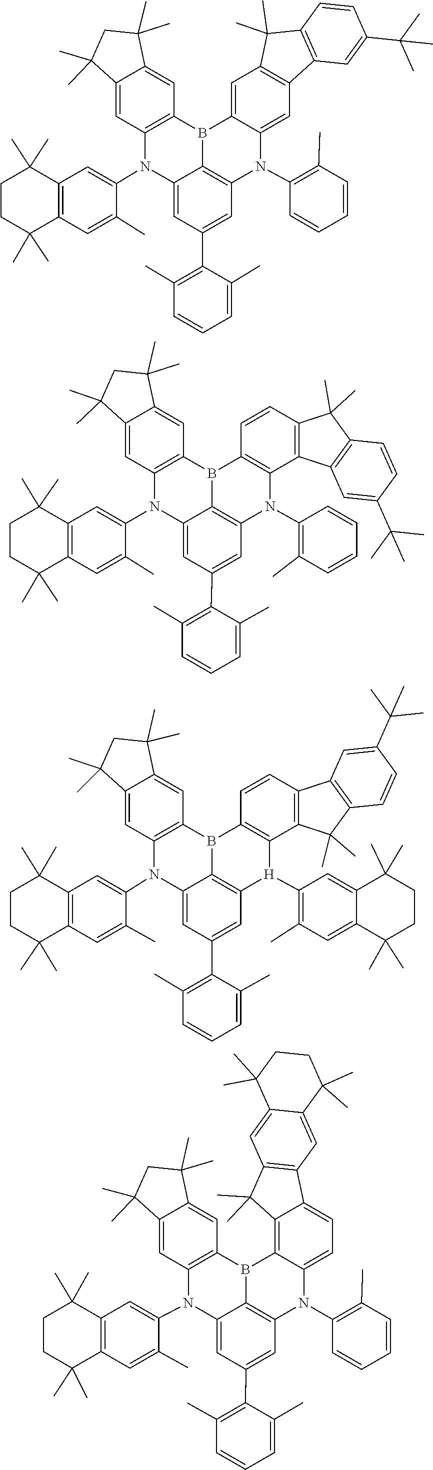

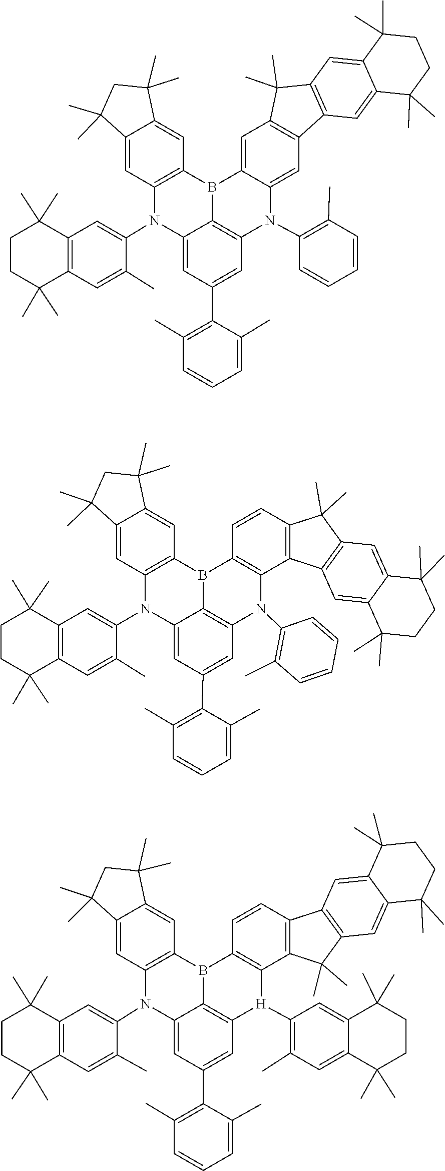

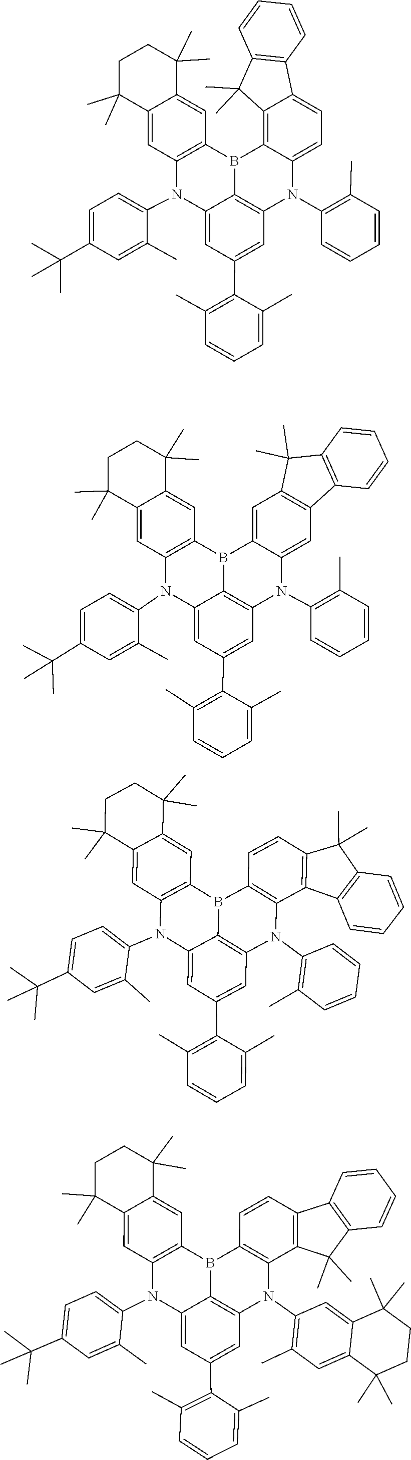

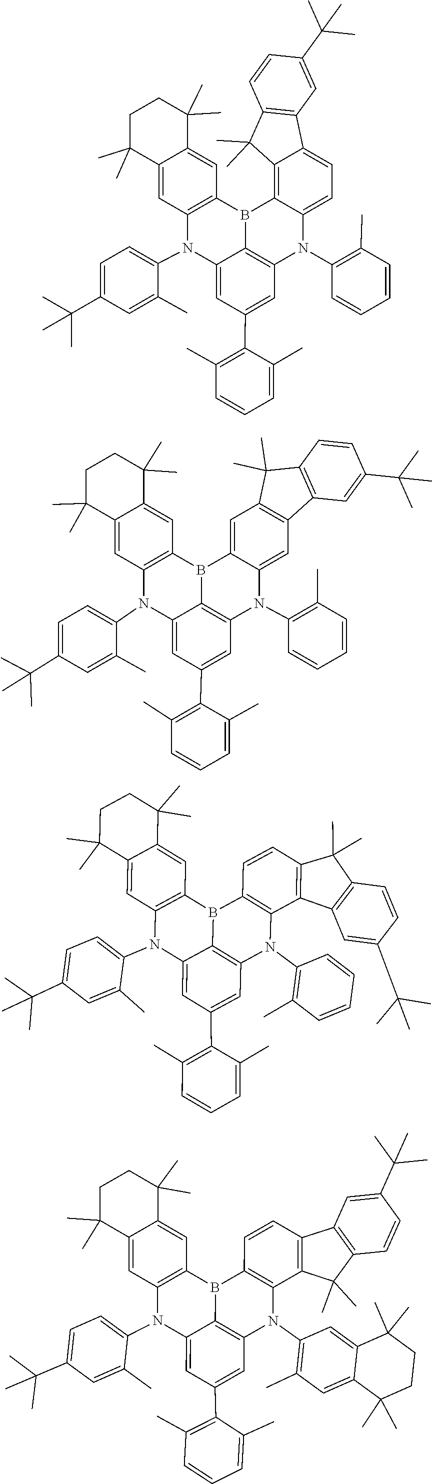

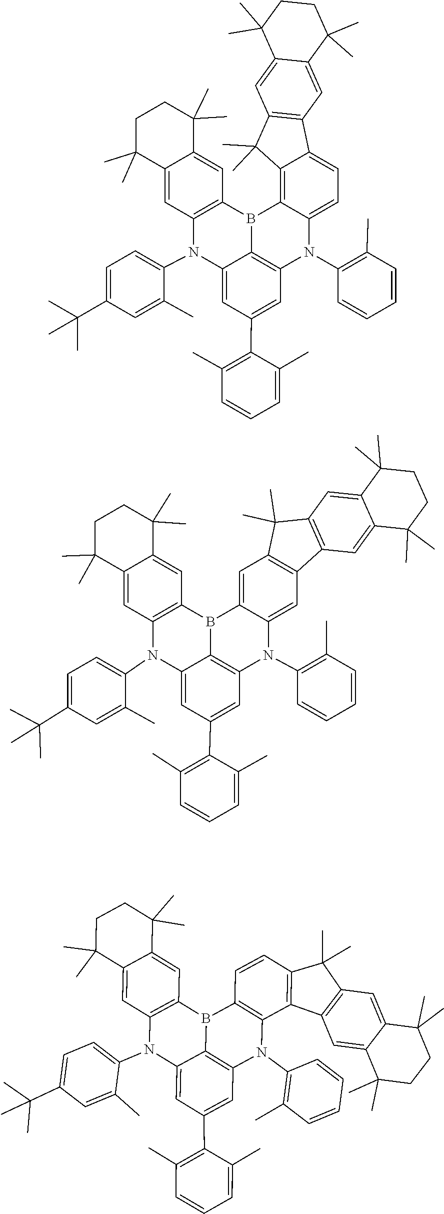

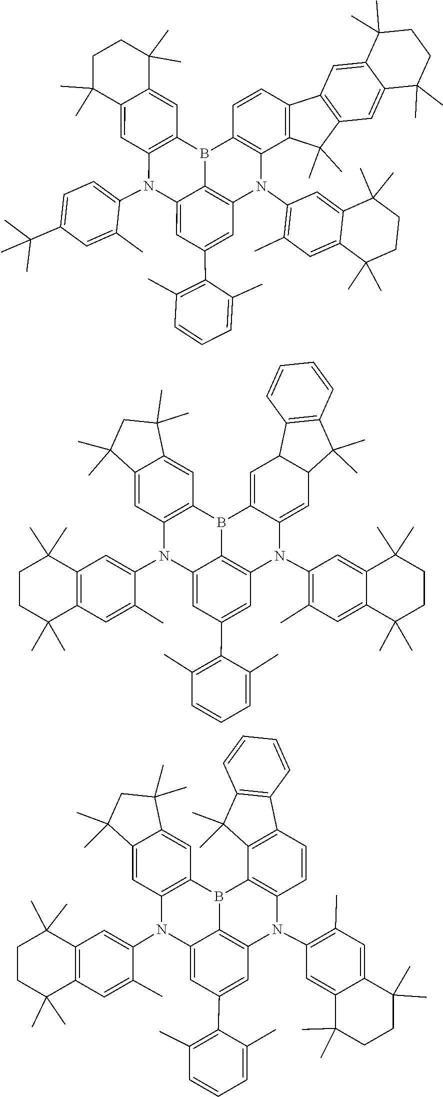

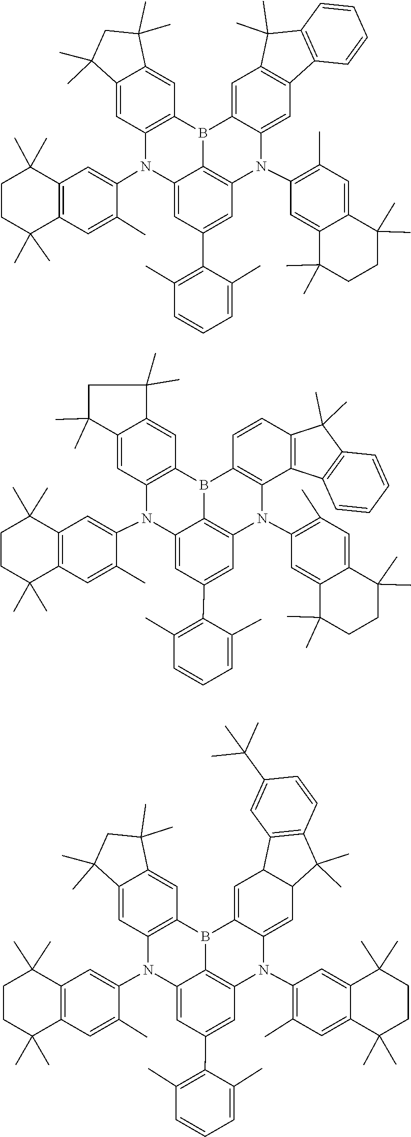

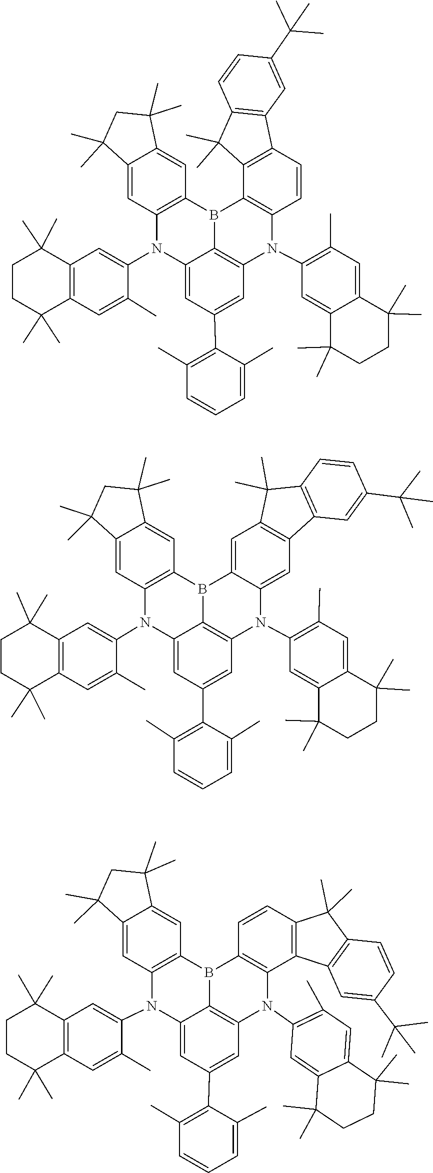 [SMILES: Cc1cc2c(cc1N1c3cc4c(cc3B3c5c1cc(-c1c(C)cccc1C)cc5N(c1cc5c(cc1C)C(C)(C)CCC5(C)C)c1ccc5c(c13)C(C)(C)c1ccc(C(C)(C)C)cc1-5)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)CC6(C)C)C(C)(C)c1ccc(C(C)(C)C)cc1-4)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)-c1cc(C(C)(C)C)ccc1C6(C)C)C(C)(C)CC4(C)C)C(C)(C)CCC2(C)C]

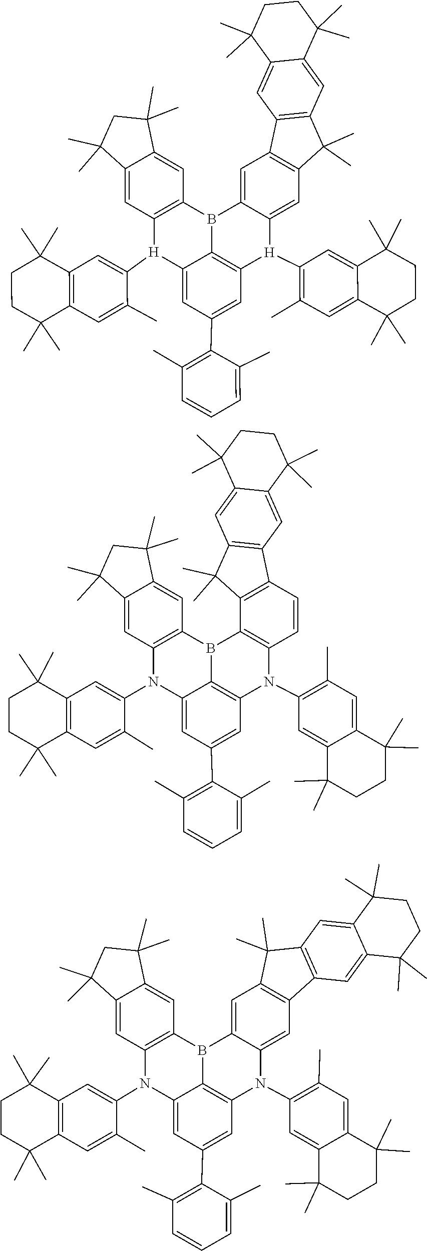

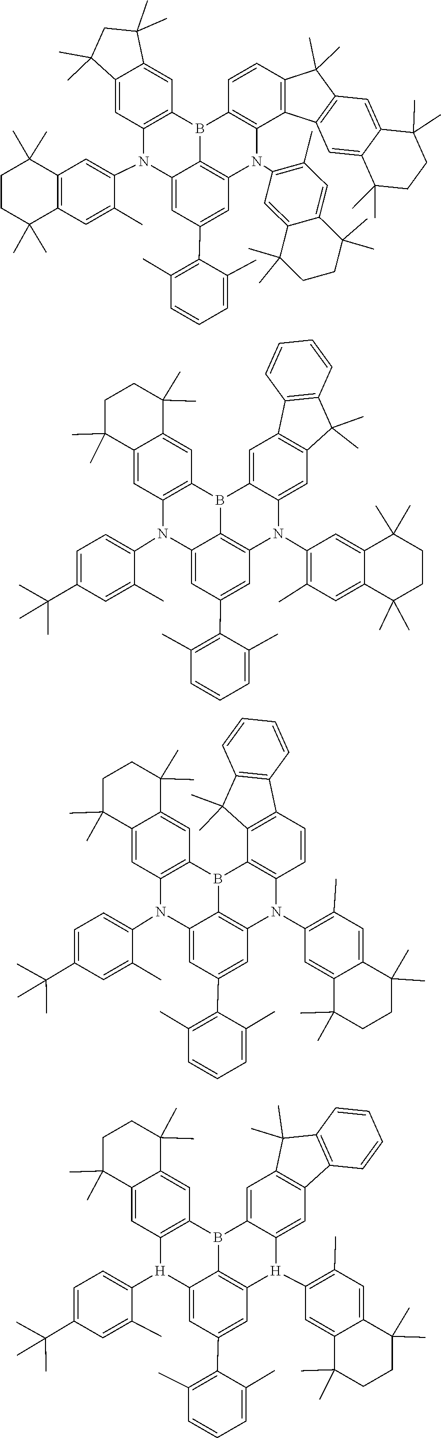

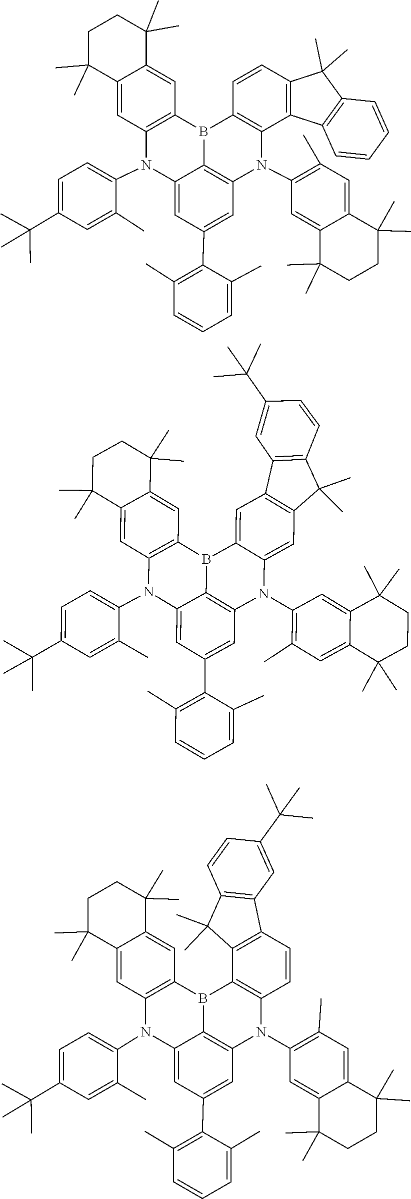

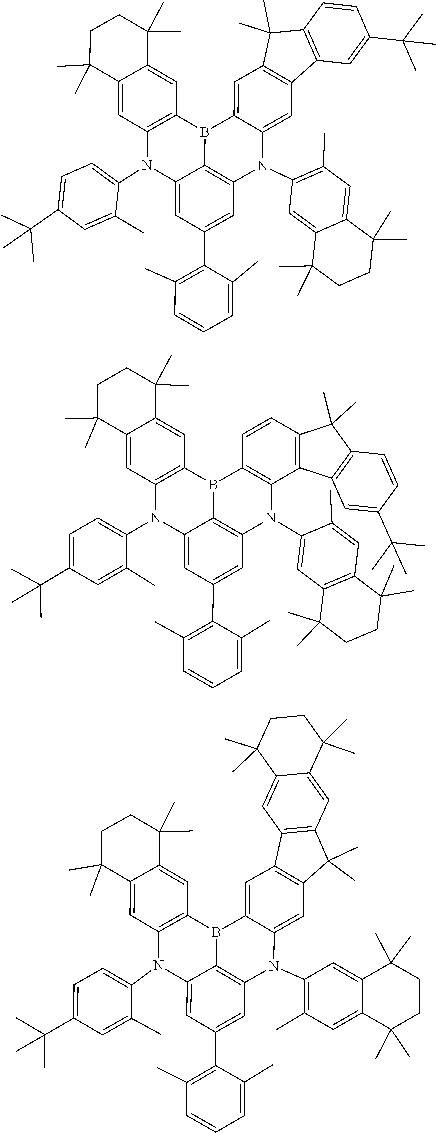

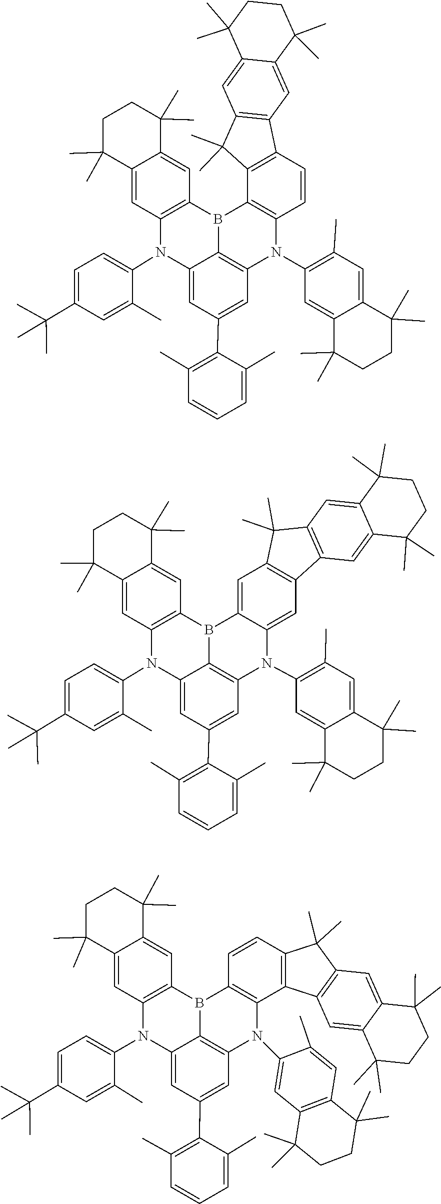

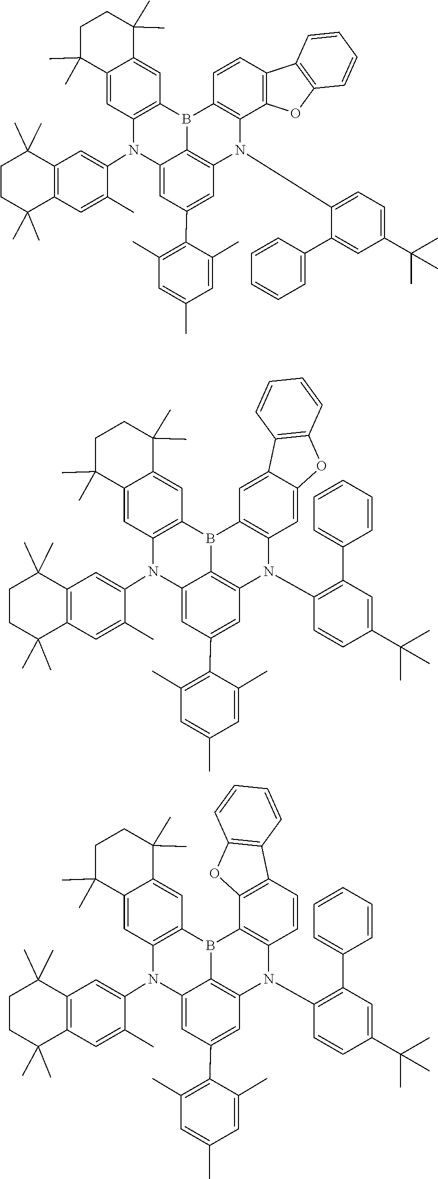

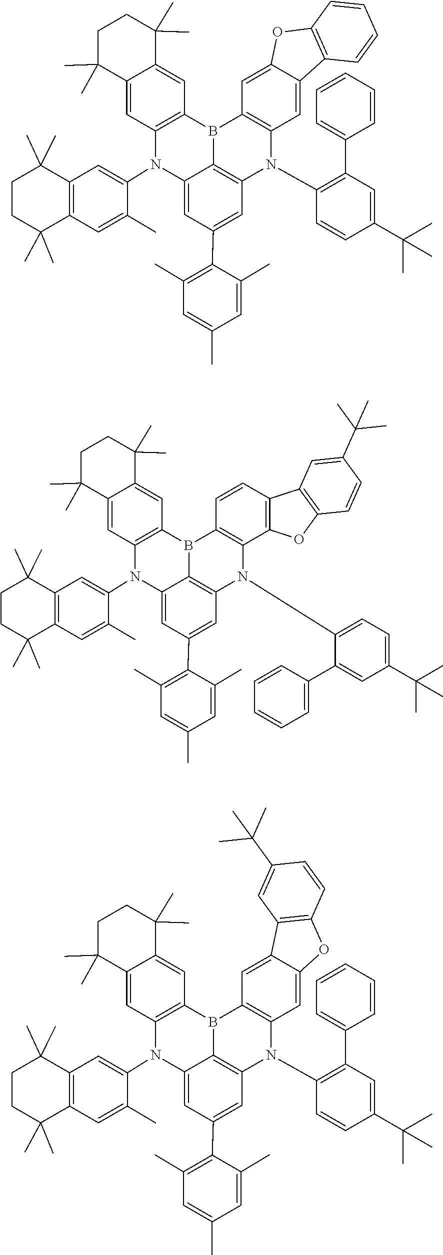 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CCC4(C)C)oc2ccccc25)c(C)c1 ; Cc1cc(C)c(-c2cc3c4c(c2)N(c2ccc(C(C)(C)C)cc2-c2ccccc2)c2c(ccc5c2oc2ccc(C(C)(C)C)cc25)B4c2cc4c(cc2N3c2cc3c(cc2C)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc4c(cc2N3c2cc3c(cc2C)C(C)(C)CCC3(C)C)C(C)(C)CCC4(C)C)c(C)c1]

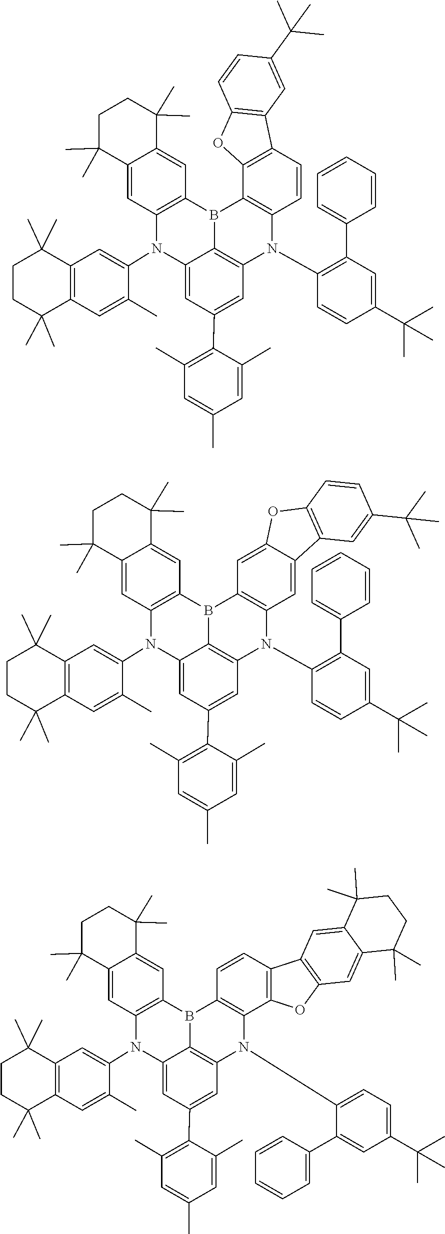 [SMILES: Cc1cc(C)c(-c2cc3c4c(c2)N(c2ccc(C(C)(C)C)cc2-c2ccccc2)c2ccc5c(oc6ccc(C(C)(C)C)cc65)c2B4c2cc4c(cc2N3c2cc3c(cc2C)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CCC4(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc4c(cc2N3c2cc3c(cc2C)C(C)(C)CCC3(C)C)C(C)(C)CCC4(C)C)c(C)c1]

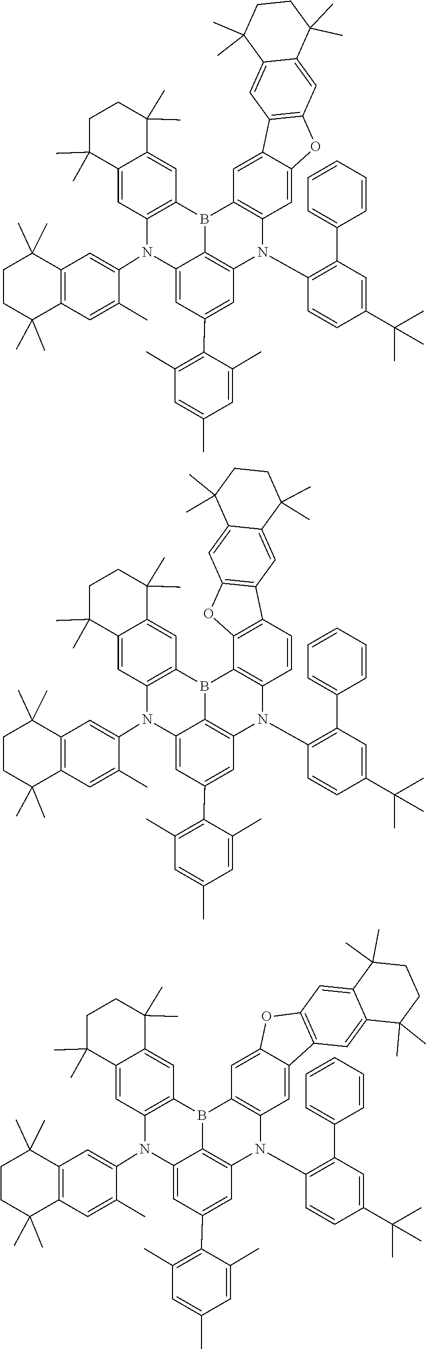

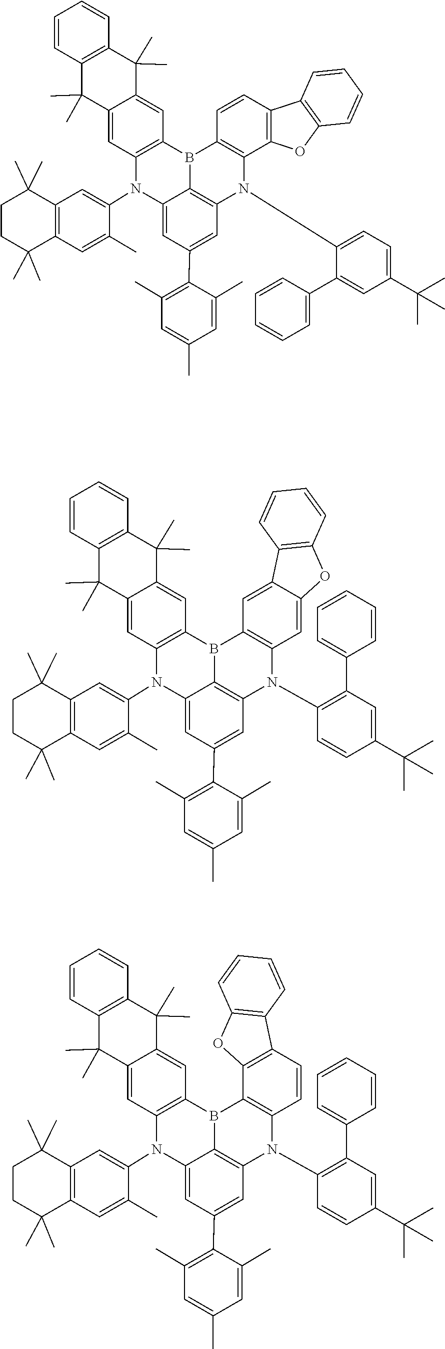 [SMILES: Cc1cc(C)c(-c2cc3c4c(c2)N(c2ccc(C(C)(C)C)cc2-c2ccccc2)c2c(ccc5c2oc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5oc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(oc6ccccc65)c2B4c2cc4c(cc2N3c2cc3c(cc2C)C(C)(C)CCC3(C)C)C(C)(C)c2ccccc2C4(C)C)c(C)c1]

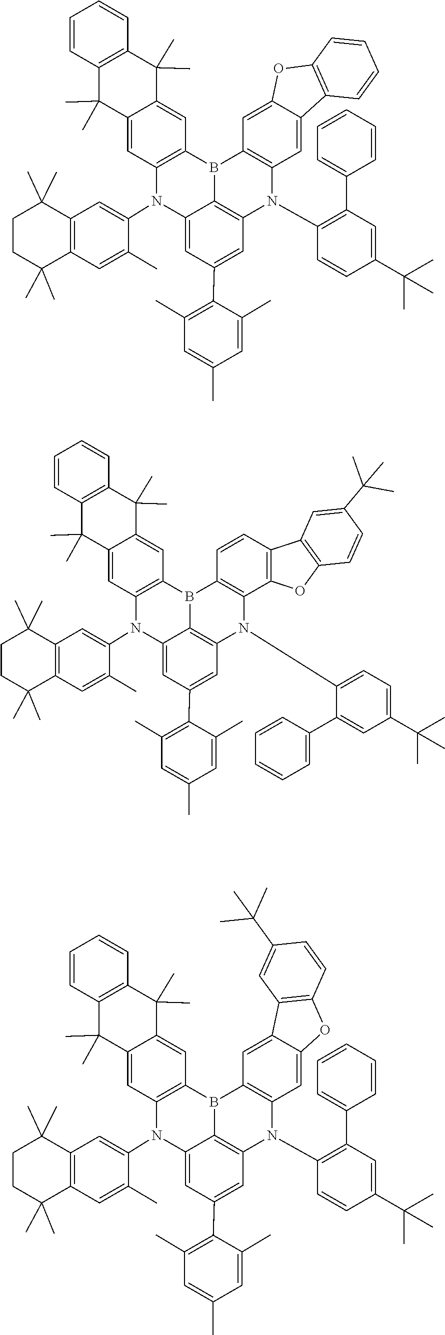 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)oc2ccccc25)c(C)c1 ; Cc1cc(C)c(-c2cc3c4c(c2)N(c2ccc(C(C)(C)C)cc2-c2ccccc2)c2c(ccc5c2oc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1]

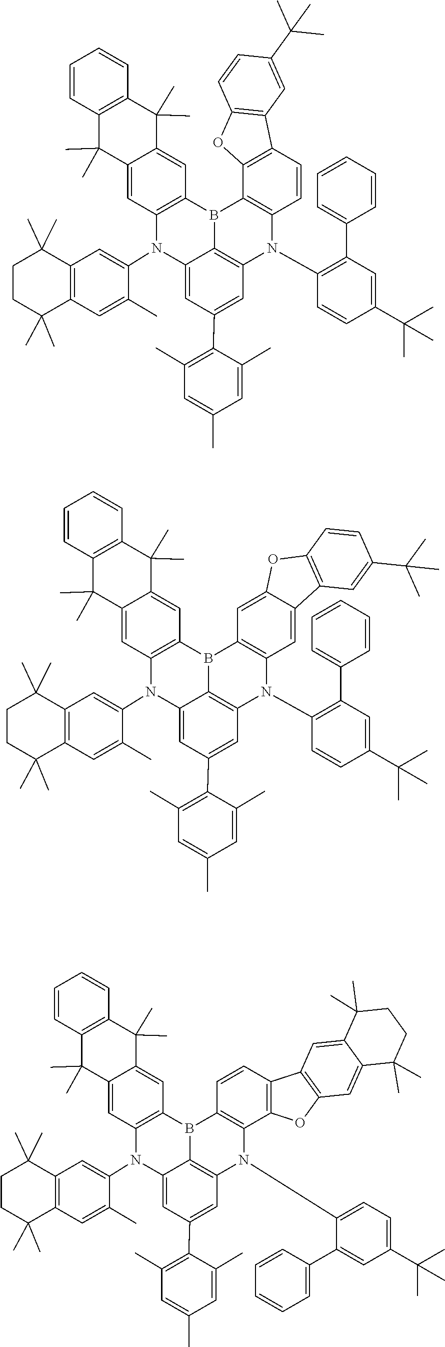 [SMILES: Cc1cc(C)c(-c2cc3c4c(c2)N(c2ccc(C(C)(C)C)cc2-c2ccccc2)c2ccc5c(oc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1]

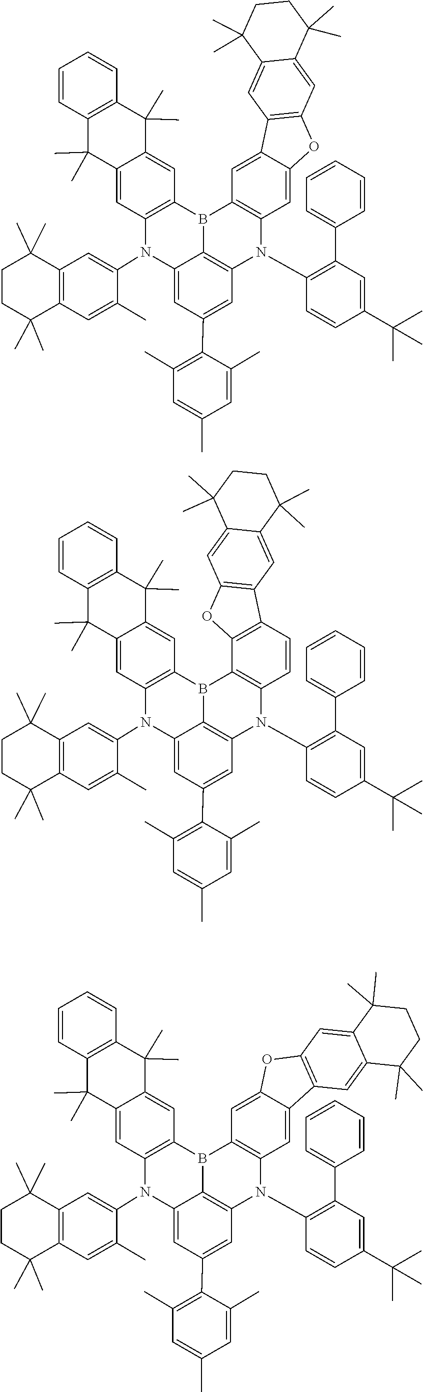

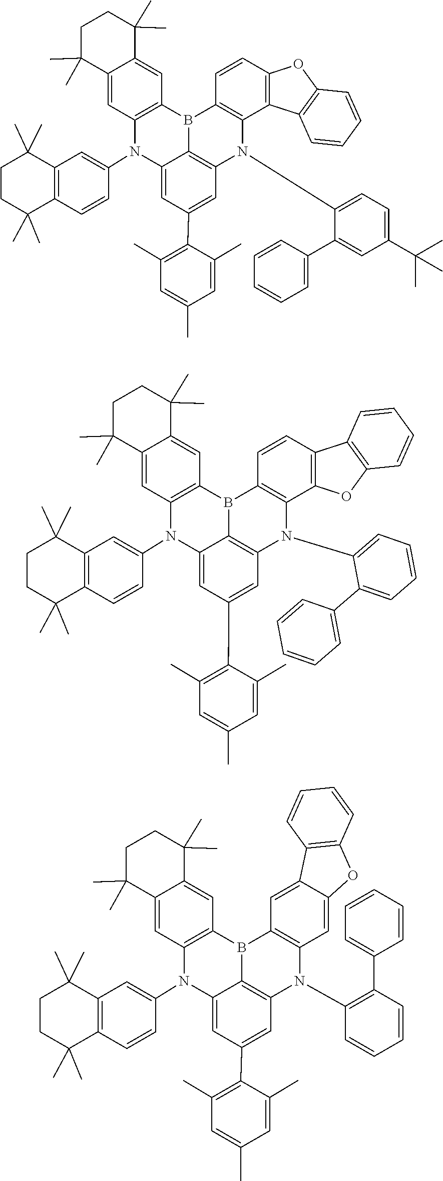

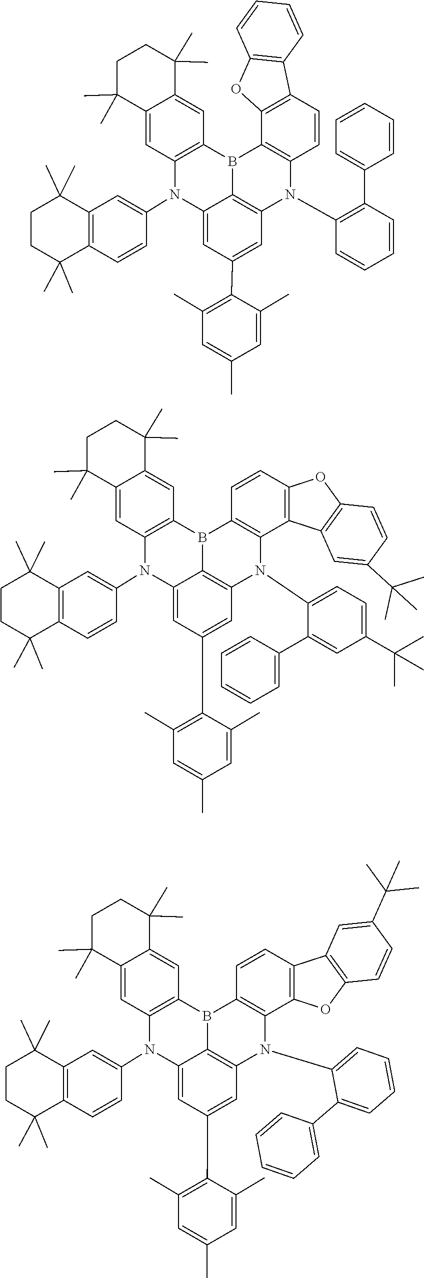 [SMILES: Cc1cc(C)c(-c2cc3c4c(c2)N(c2ccccc2-c2ccccc2)c2ccc5c(oc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2c(ccc5oc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc4c(cc2N3c2ccc3c(c2)C(C)(C)CCC3(C)C)C(C)(C)CCC4(C)C)c(C)c1]

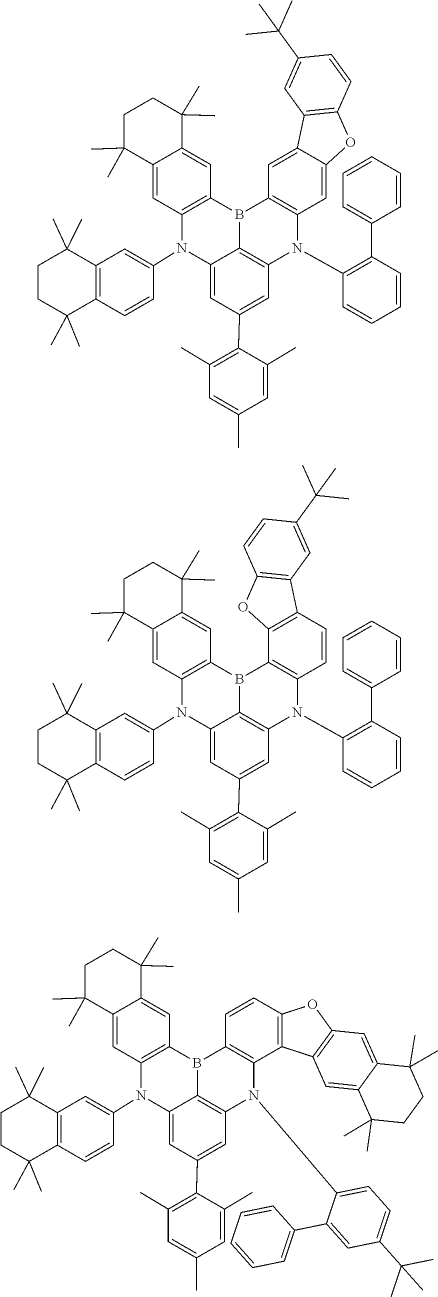 [SMILES: Cc1cc(C)c(-c2cc3c4c(c2)N(c2ccccc2-c2ccccc2)c2cc5oc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2ccc5c(oc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

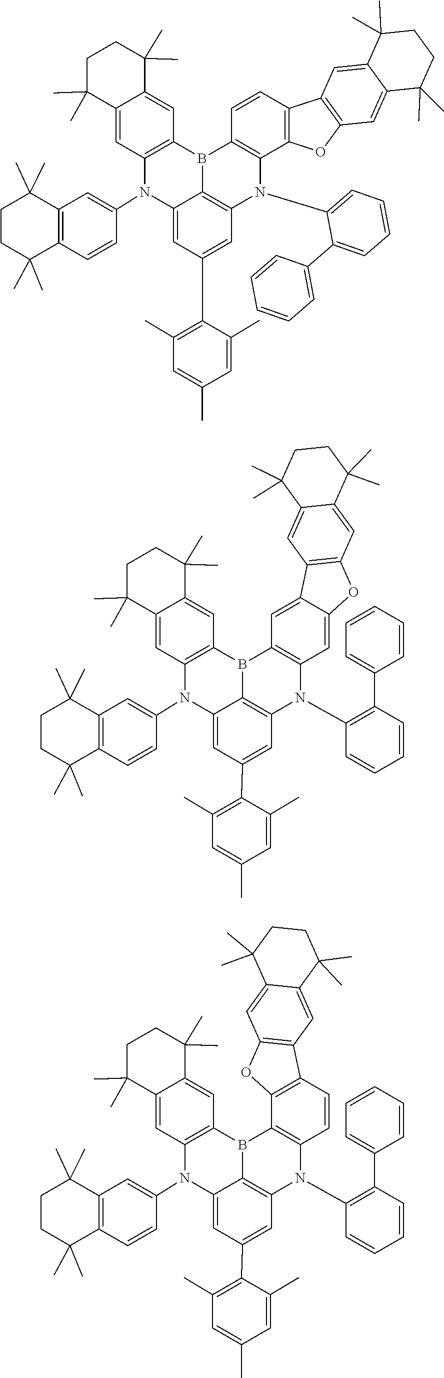

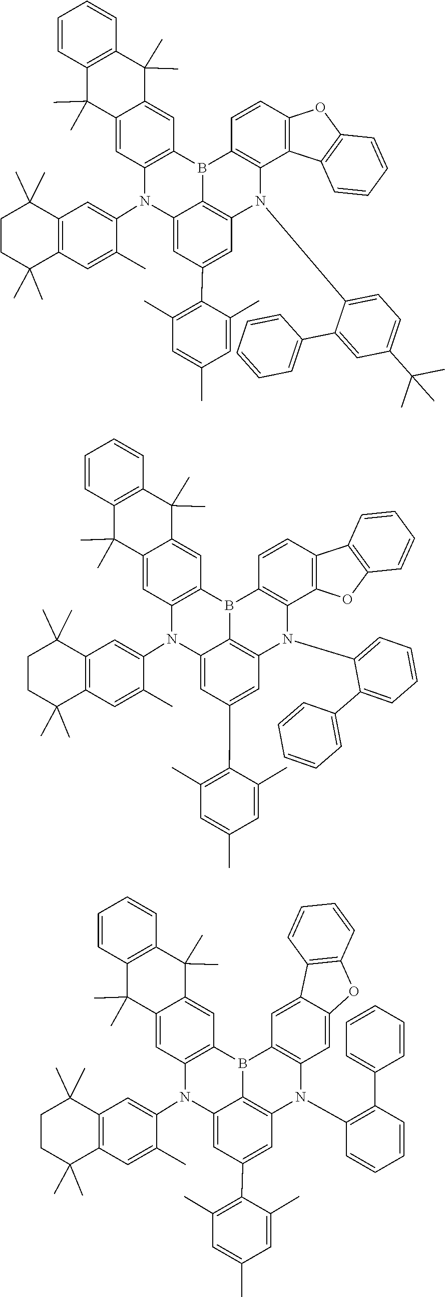 [SMILES: Cc1cc(C)c(-c2cc3c4c(c2)N(c2ccc(C(C)(C)C)cc2-c2ccccc2)c2c(ccc5oc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2oc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5oc6ccccc6c5cc2B4c2cc4c(cc2N3c2cc3c(cc2C)C(C)(C)CCC3(C)C)C(C)(C)c2ccccc2C4(C)C)c(C)c1]

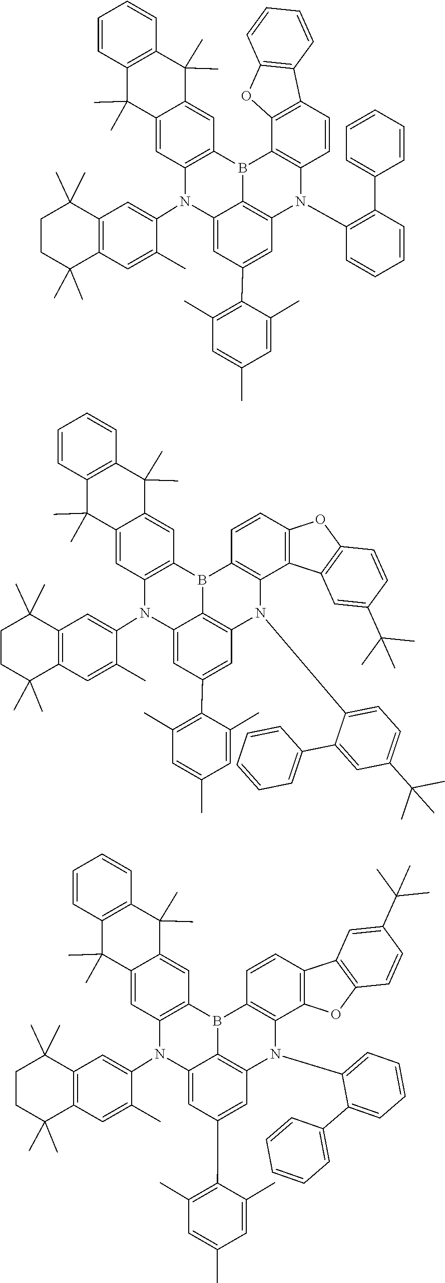 [SMILES: Cc1cc(C)c(-c2cc3c4c(c2)N(c2ccccc2-c2ccccc2)c2ccc5c(oc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5oc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc4c(cc2N3c2cc3c(cc2C)C(C)(C)CCC3(C)C)C(C)(C)c2ccccc2C4(C)C)c(C)c1]

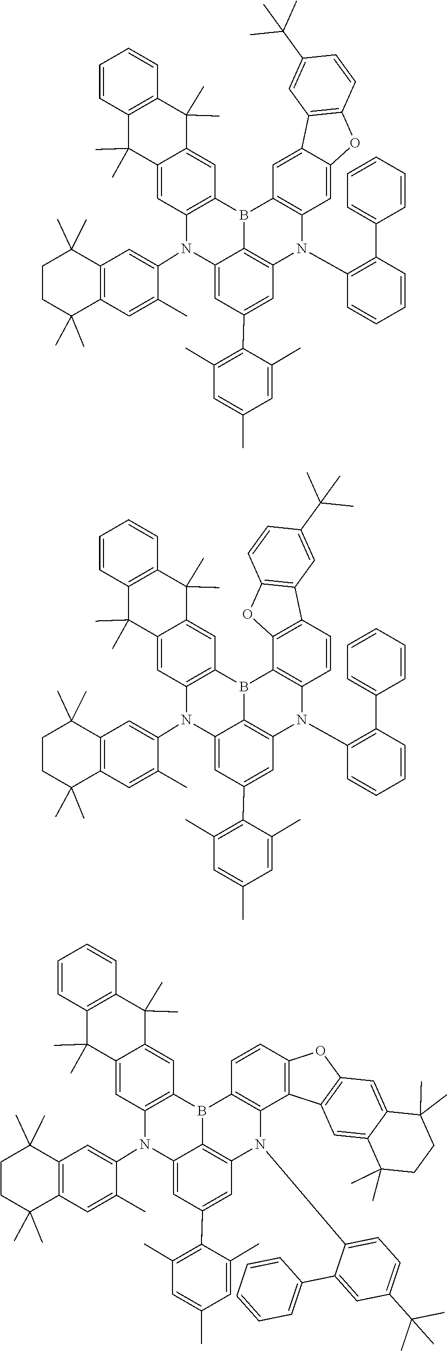 [SMILES: Cc1cc(C)c(-c2cc3c4c(c2)N(c2ccccc2-c2ccccc2)c2cc5oc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2ccc5c(oc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1]

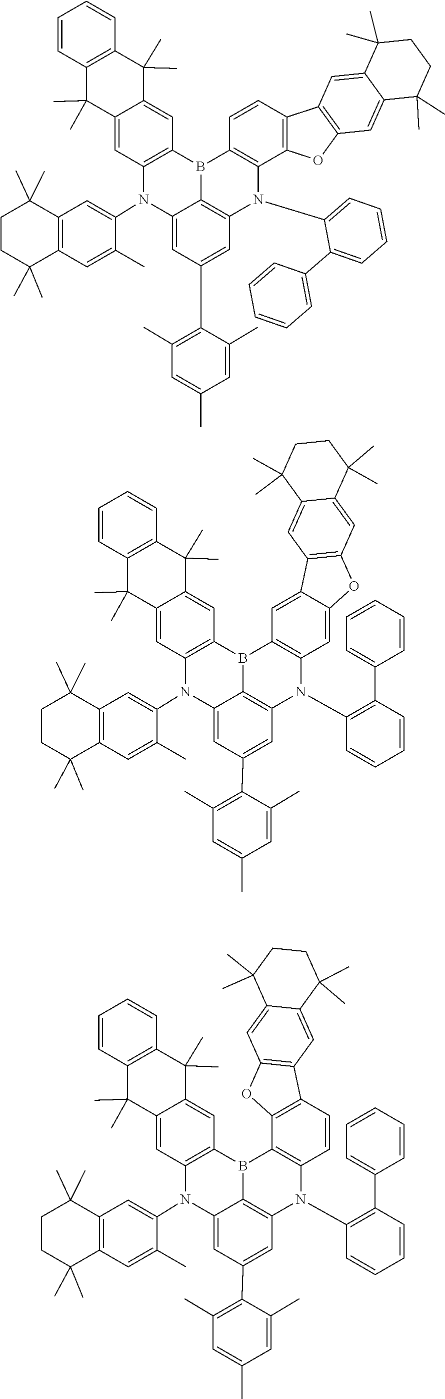 [SMILES: Cc1cc(C)c(-c2cc3c4c(c2)N(c2ccccc2-c2ccccc2)c2c(ccc5c2oc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5oc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1 ; Cc1cc(C)c(-c2cc3c4c(c2)N(c2ccccc2-c2ccccc2)c2ccc5c(oc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1]

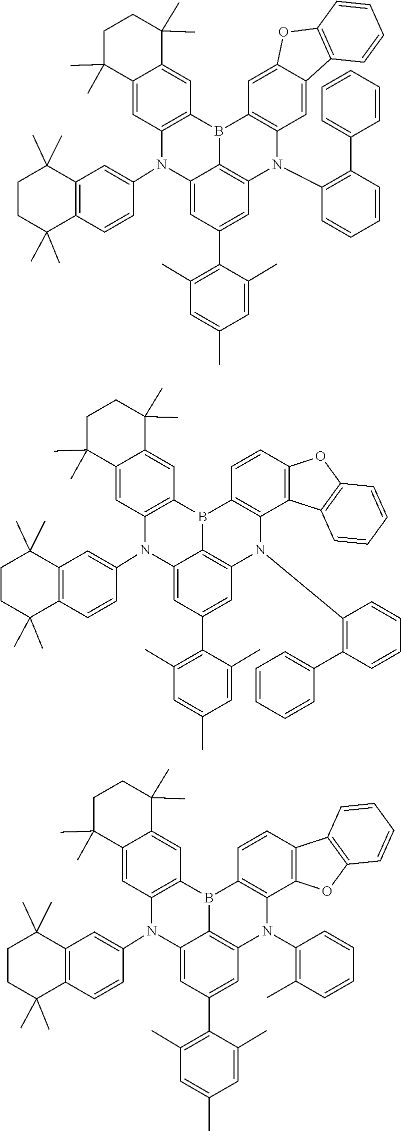

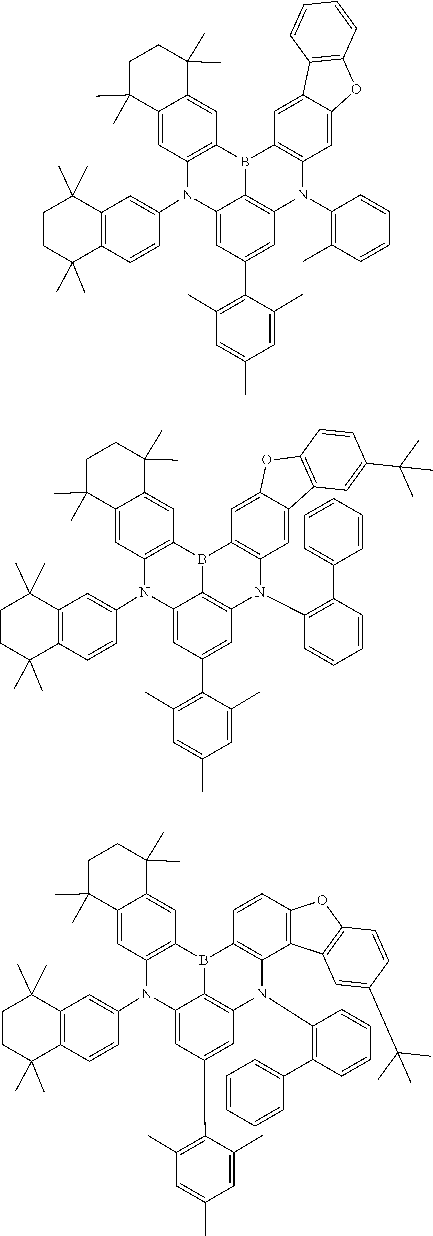 [SMILES: Cc1cc(C)c(-c2cc3c4c(c2)N(c2ccccc2C)c2cc5oc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2ccc(C(C)(C)C)cc25)c(C)c1 ; Cc1cc(C)c(-c2cc3c4c(c2)N(c2ccccc2-c2ccccc2)c2c(ccc5oc6ccc(C(C)(C)C)cc6c25)B4c2cc4c(cc2N3c2ccc3c(c2)C(C)(C)CCC3(C)C)C(C)(C)CCC4(C)C)c(C)c1]

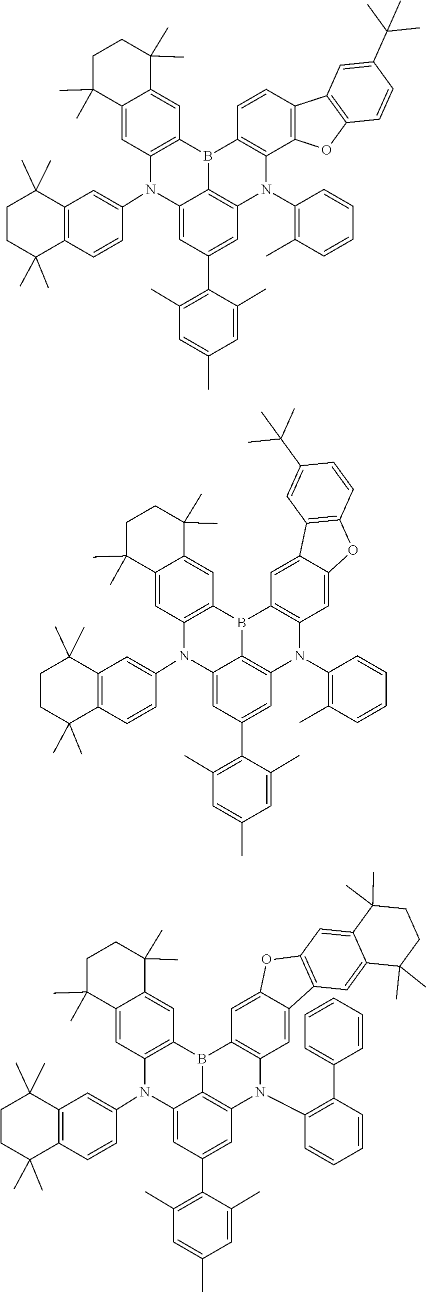 [SMILES: Cc1cc(C)c(-c2cc3c4c(c2)N(c2ccccc2C)c2c(ccc5c2oc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5oc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)c(C)c1]

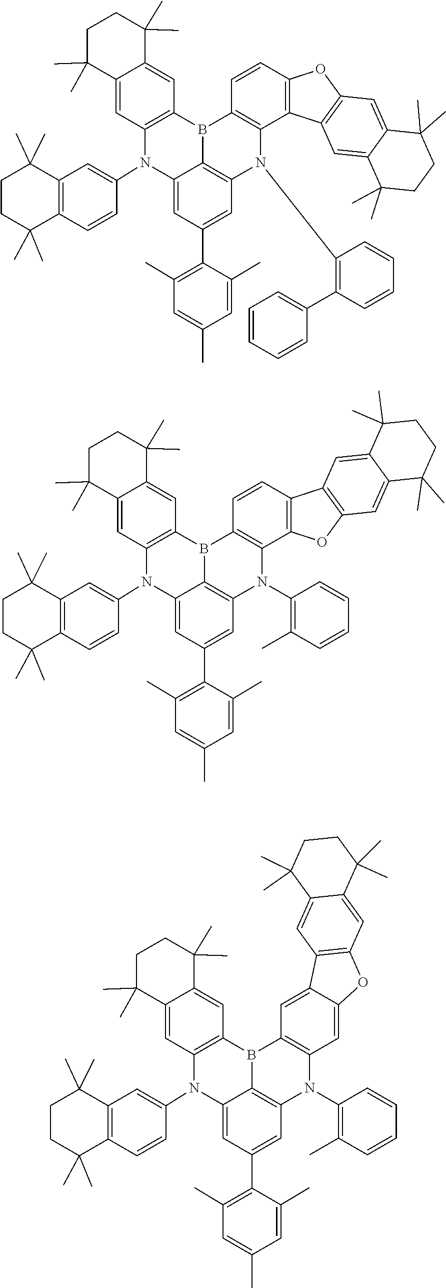 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5oc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

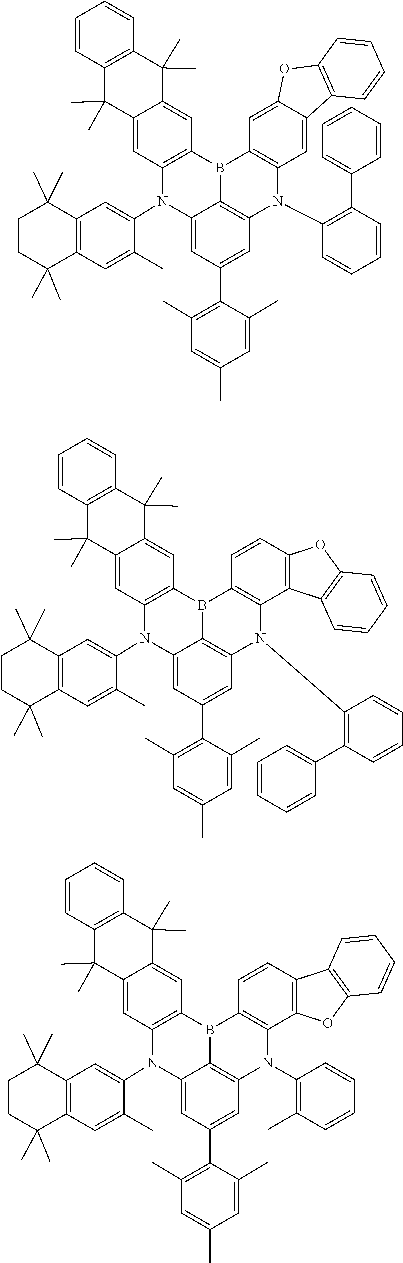 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2oc2ccccc25)B4c2cc4c(cc2N3c2cc3c(cc2C)C(C)(C)CCC3(C)C)C(C)(C)c2ccccc2C4(C)C)c(C)c1]

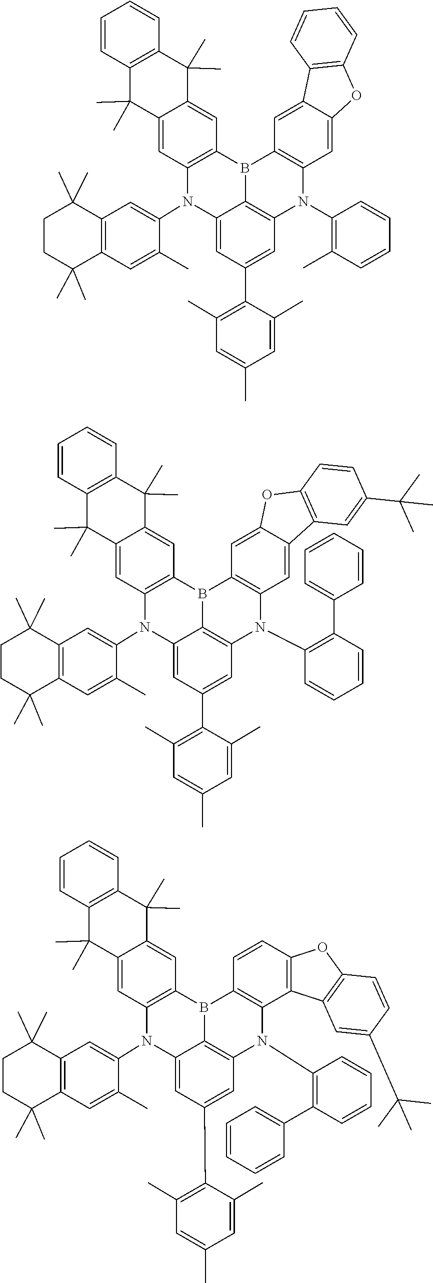 [SMILES: Cc1cc(C)c(-c2cc3c4c(c2)N(c2ccccc2C)c2cc5oc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)oc2ccc(C(C)(C)C)cc25)c(C)c1 ; Cc1cc(C)c(-c2cc3c4c(c2)N(c2ccccc2-c2ccccc2)c2c(ccc5oc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1]

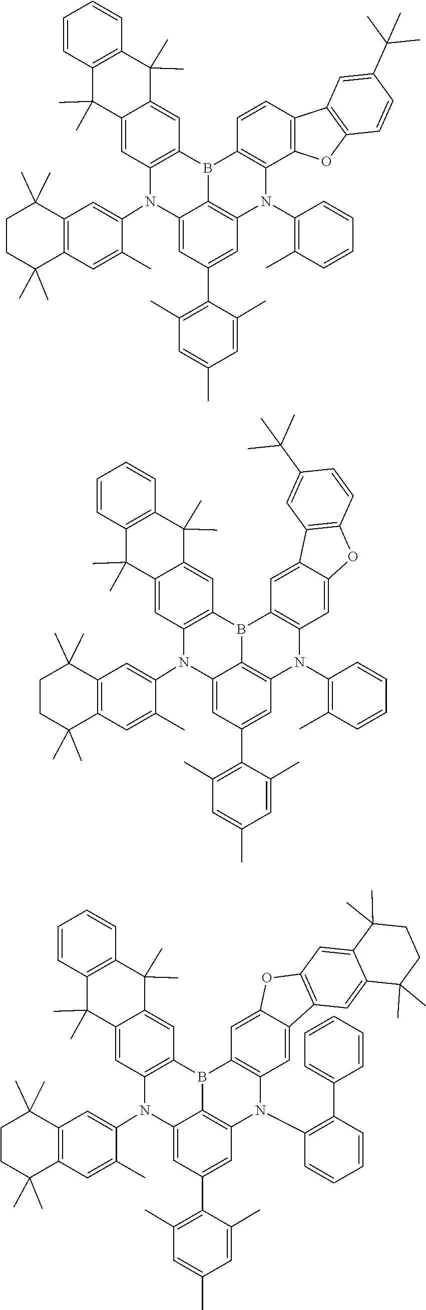 [SMILES: Cc1cc(C)c(-c2cc3c4c(c2)N(c2ccccc2C)c2c(ccc5c2oc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5oc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)oc2cc3c(cc25)C(C)(C)CCC3(C)C)c(C)c1]

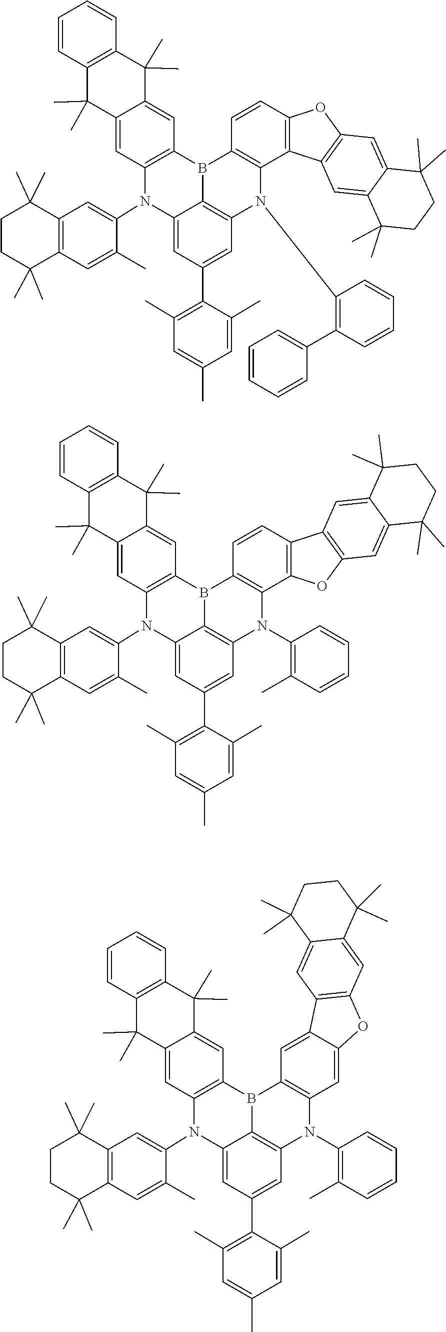 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5oc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1]

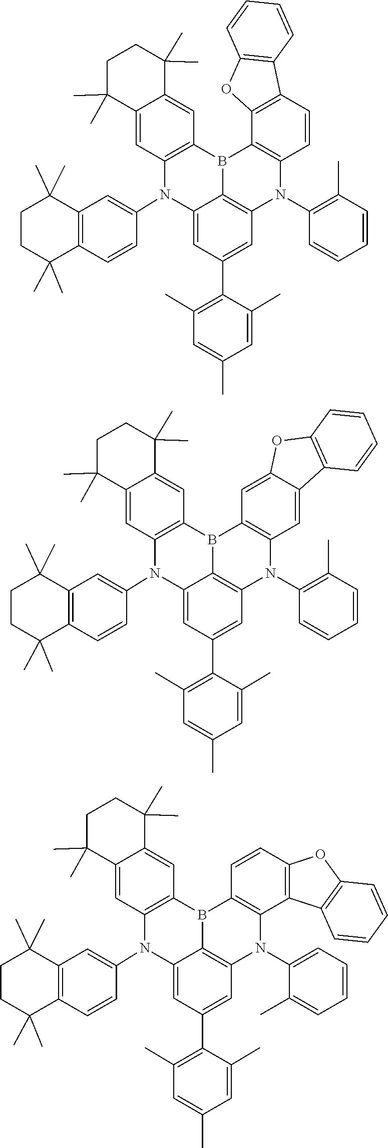 [SMILES: Cc1cc(C)c(-c2cc3c4c(c2)N(c2ccccc2C)c2ccc5c(oc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2ccc3c(c2)C(C)(C)CCC3(C)C)C(C)(C)CCC4(C)C)c(C)c1]

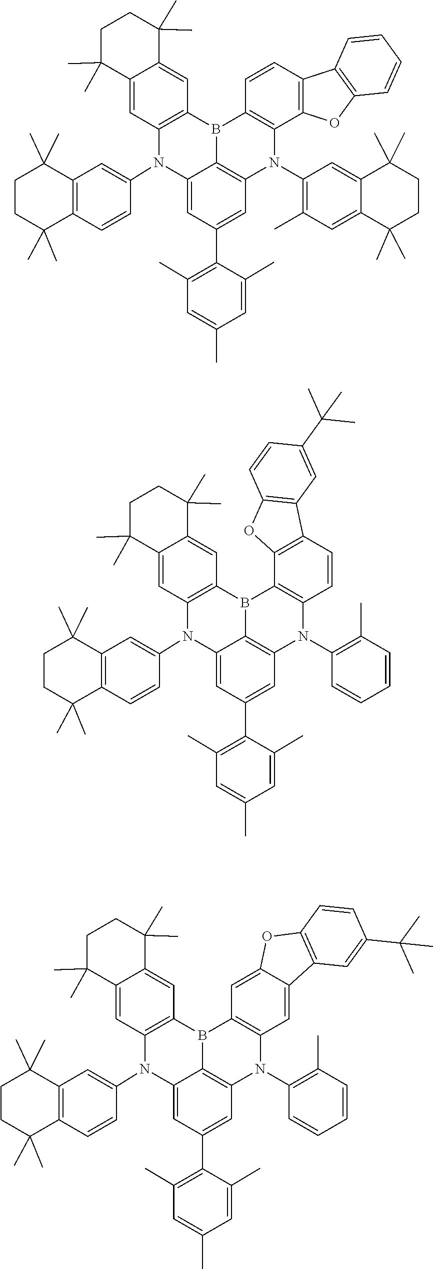 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)oc2ccc(C(C)(C)C)cc25)c(C)c1]

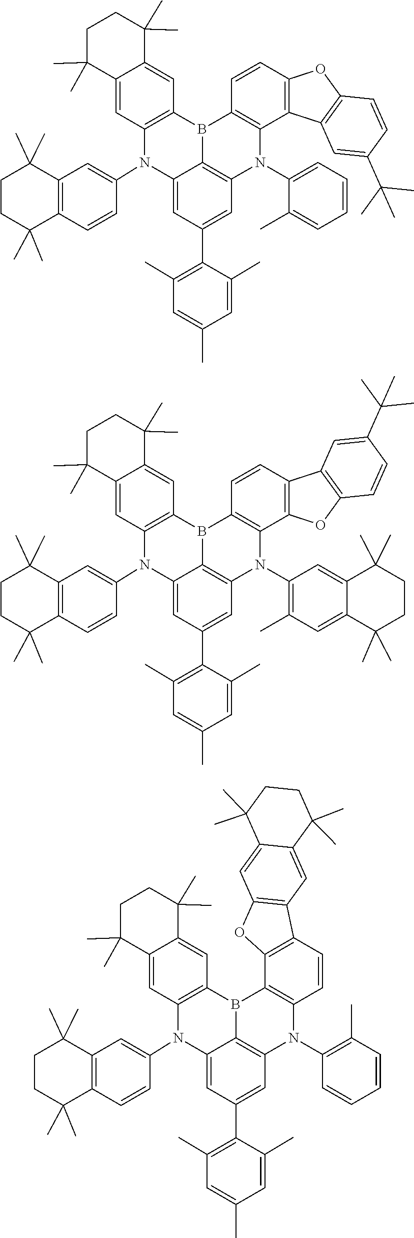

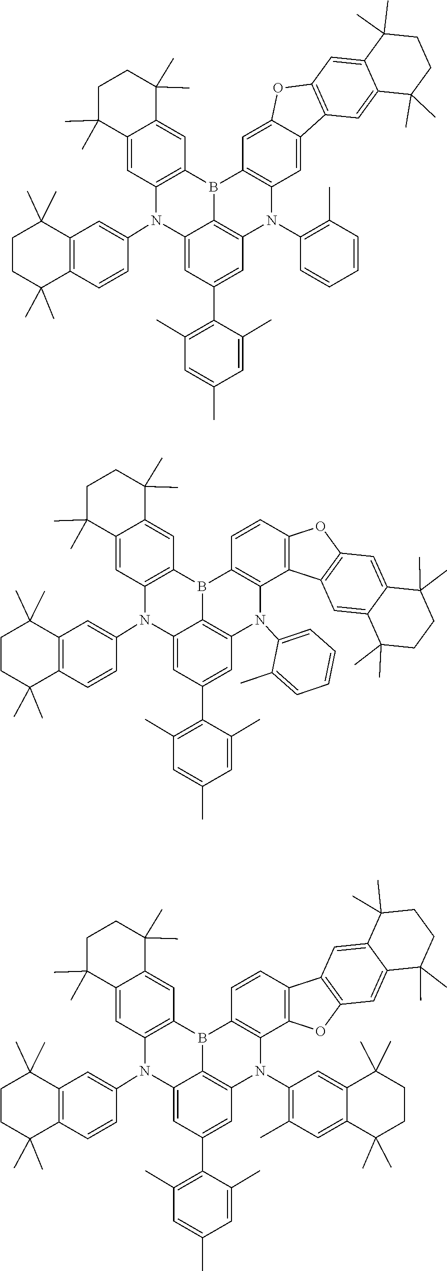 [SMILES: Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1]

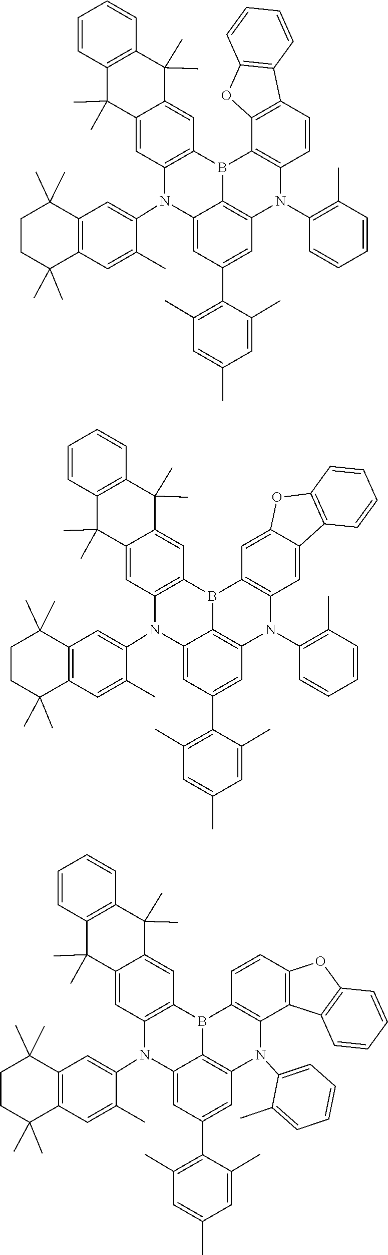 [SMILES: Cc1cc(C)c(-c2cc3c4c(c2)N(c2ccccc2C)c2ccc5c(oc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2cc3c(cc2C)C(C)(C)CCC3(C)C)C(C)(C)c2ccccc2C4(C)C)c(C)c1]

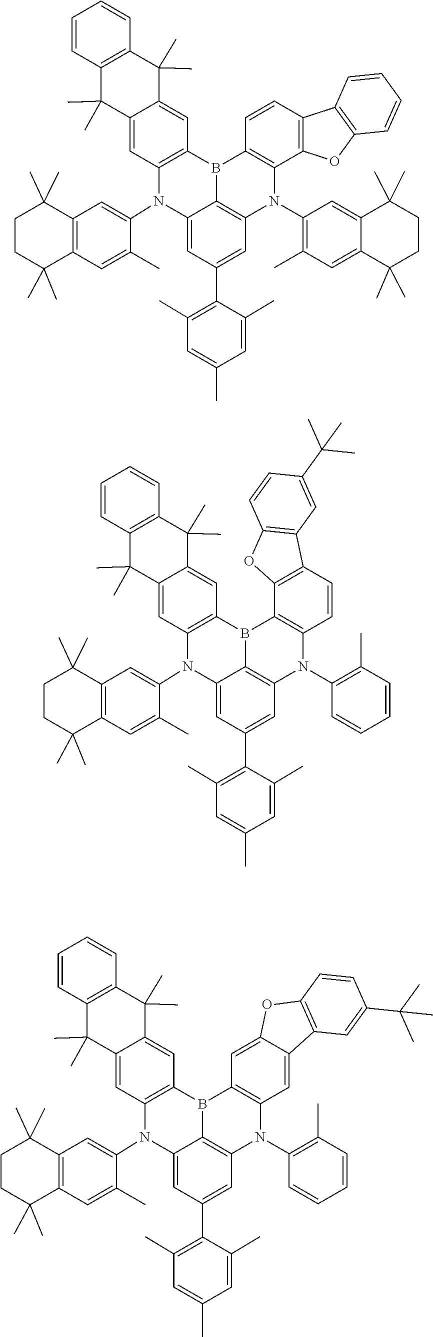 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)oc2ccc(C(C)(C)C)cc25)c(C)c1]

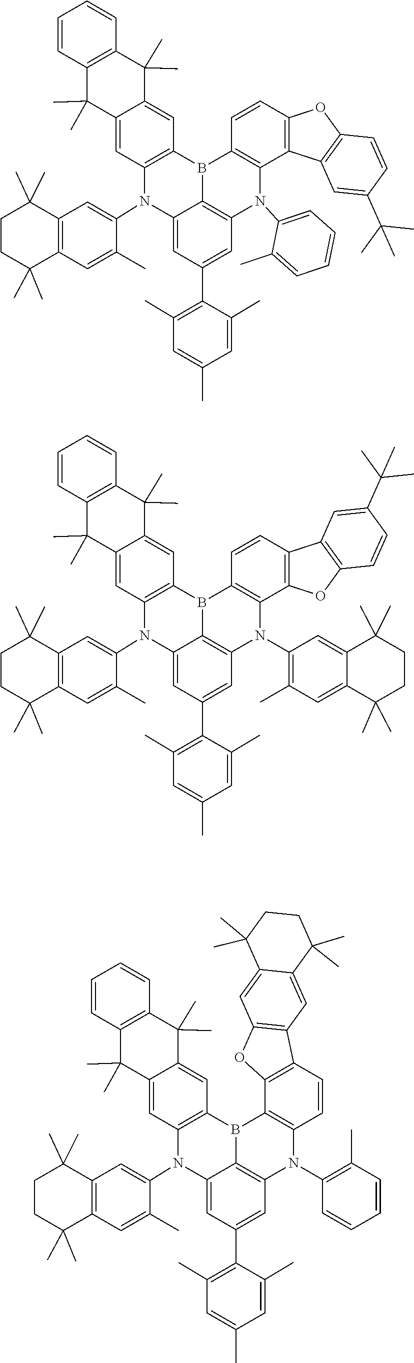 [SMILES: Cc1cc(C)c(-c2cc3c4c(c2)N(c2ccccc2C)c2c(ccc5oc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2oc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(oc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1]

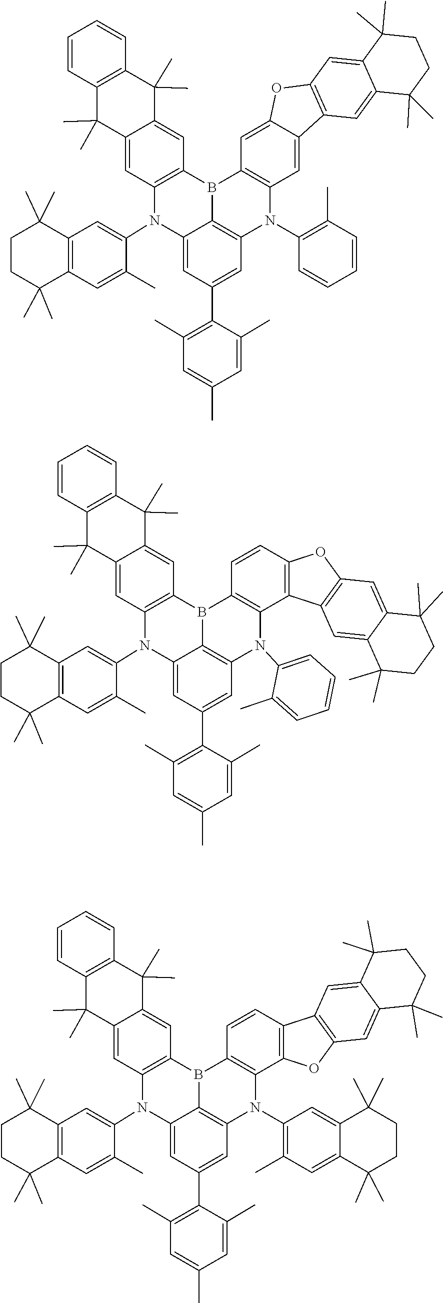 [SMILES: Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1]

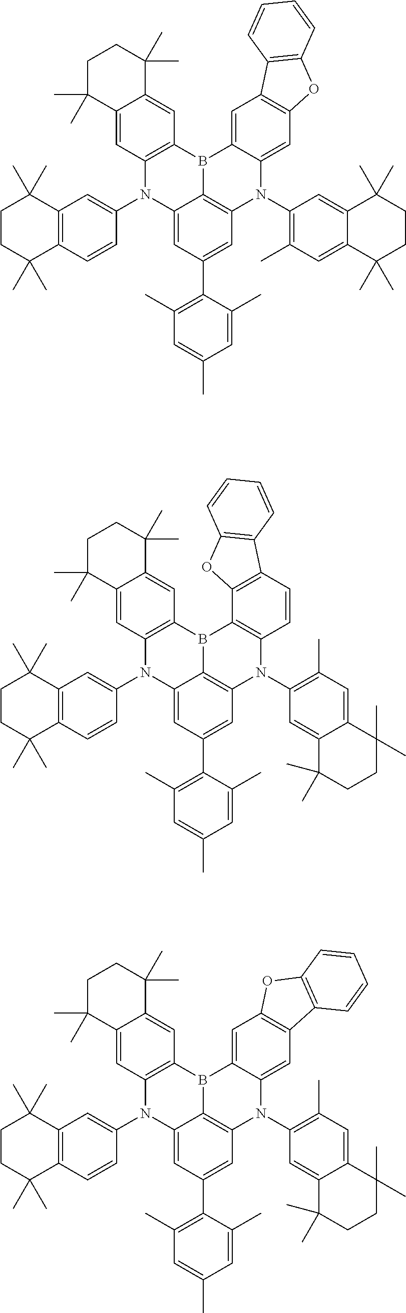 [SMILES: Cc1cc(C)c(-c2cc3c4c(c2)N(c2cc5c(cc2C)C(C)(C)CCC5(C)C)c2cc5oc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccc5c(oc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2ccccc25)c(C)c1]

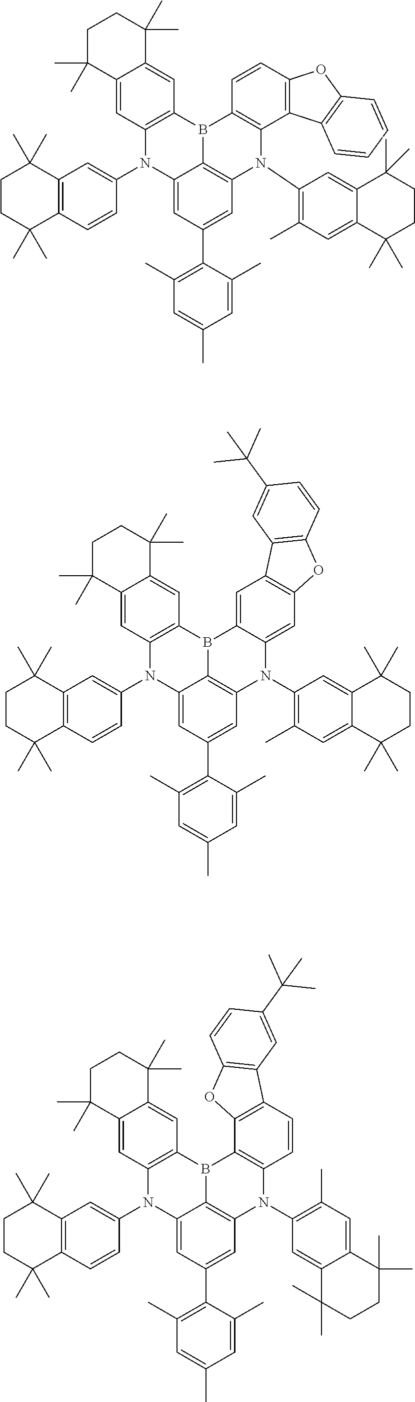 [SMILES: Cc1cc(C)c(-c2cc3c4c(c2)N(c2cc5c(cc2C)C(C)(C)CCC5(C)C)c2c(ccc5oc6ccccc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5oc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccc5c(oc6ccc(C(C)(C)C)cc65)c2B4c2cc4c(cc2N3c2ccc3c(c2)C(C)(C)CCC3(C)C)C(C)(C)CCC4(C)C)c(C)c1]

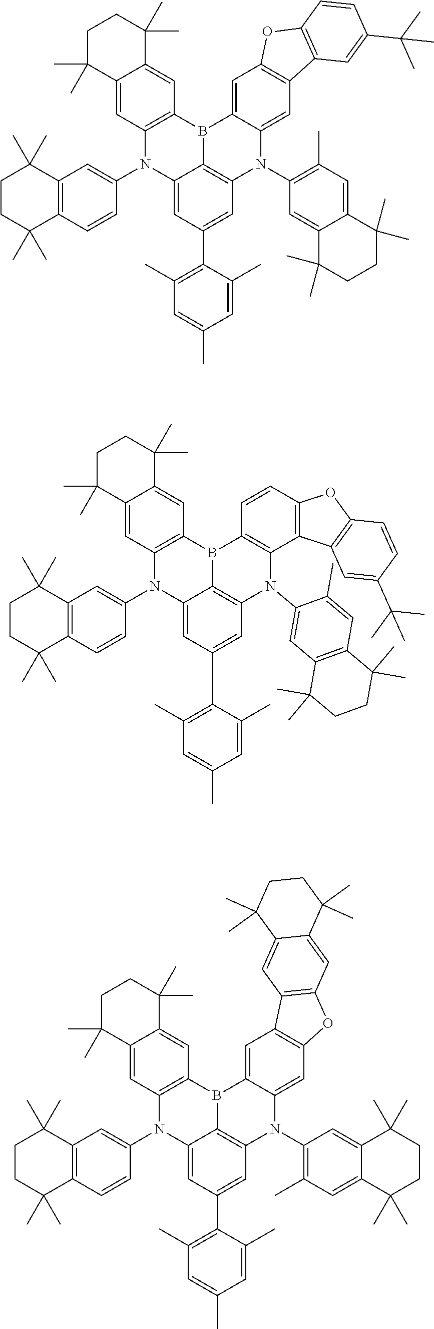 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

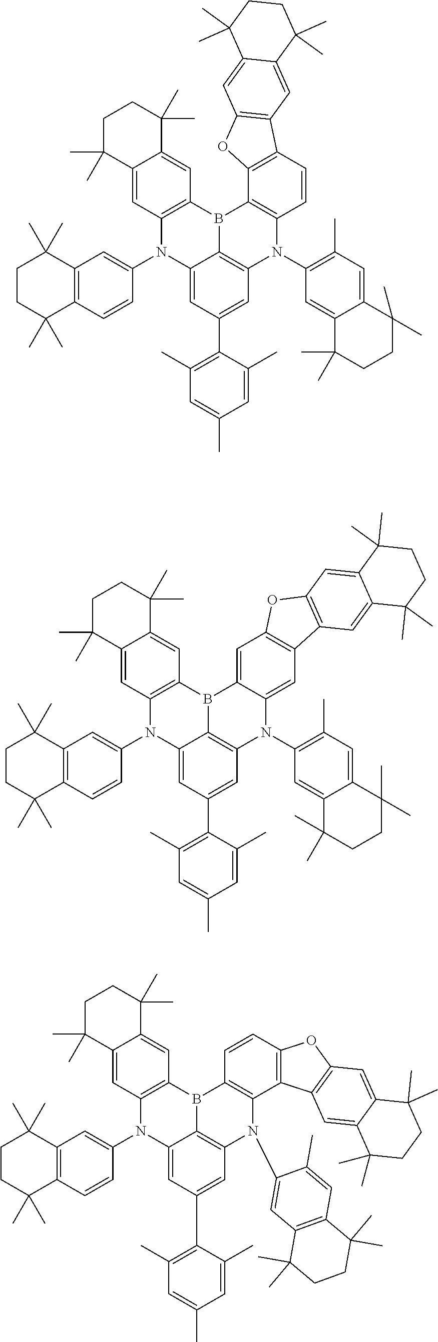 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

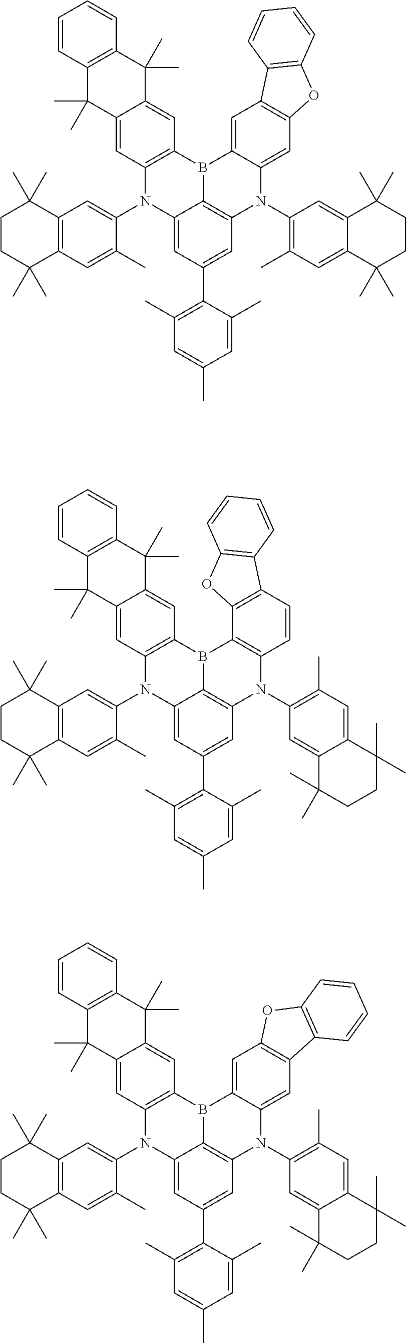 [SMILES: Cc1cc(C)c(-c2cc3c4c(c2)N(c2cc5c(cc2C)C(C)(C)CCC5(C)C)c2cc5oc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)oc2ccccc25)c(C)c1]

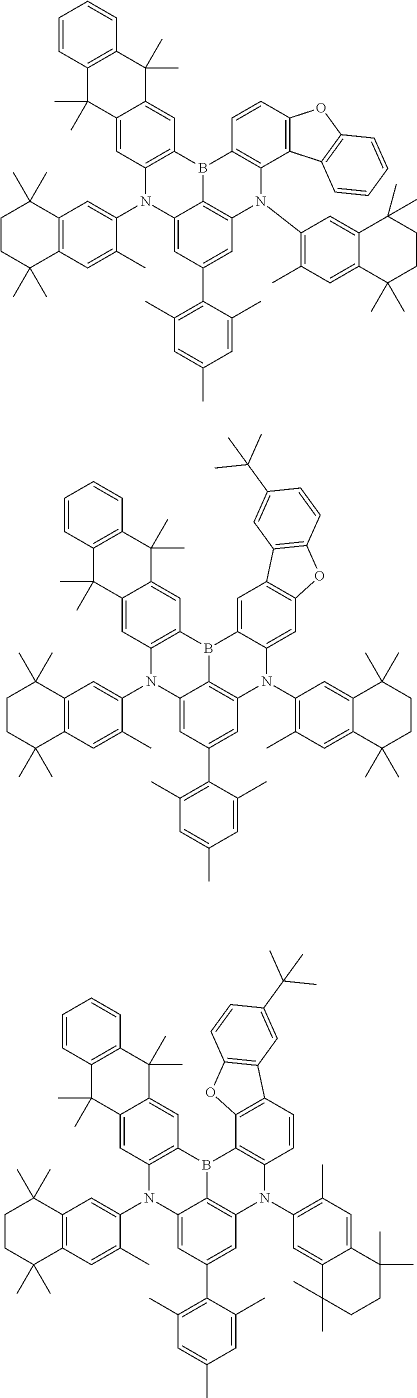

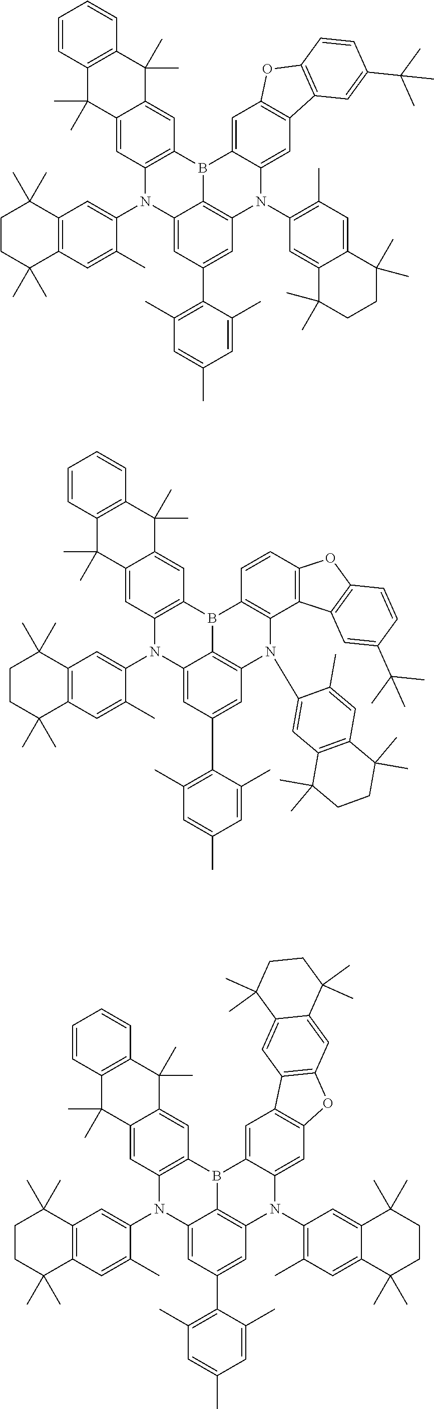 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1]

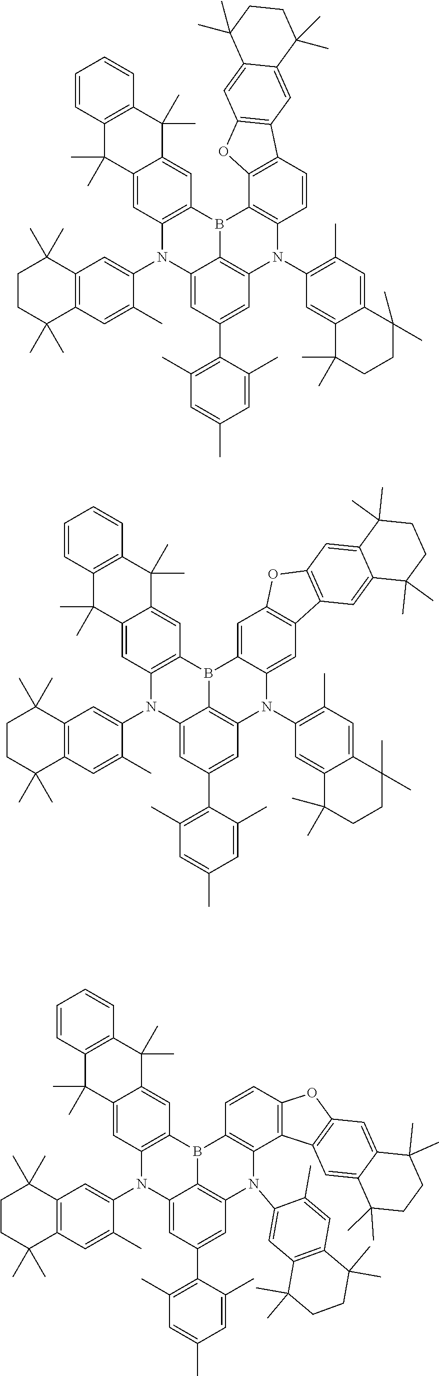 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1]

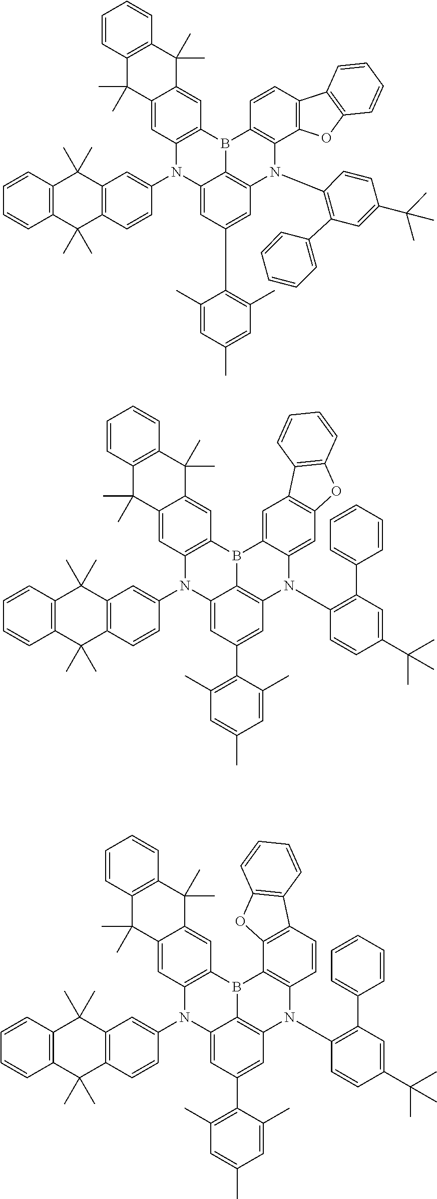 [SMILES: Cc1cc(C)c(-c2cc3c4c(c2)N(c2ccc(C(C)(C)C)cc2-c2ccccc2)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1]

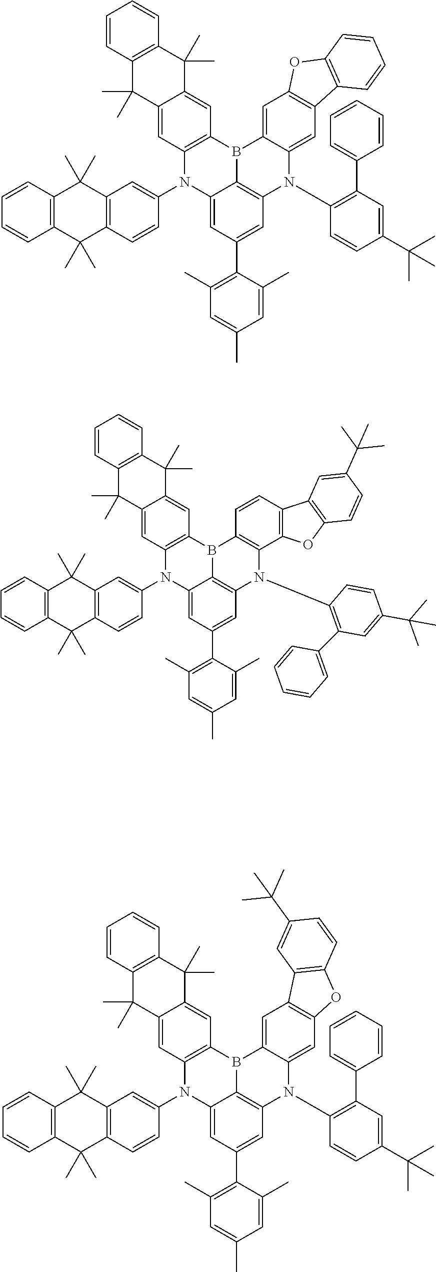 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1 ; Cc1cc(C)c(-c2cc3c4c(c2)N(c2ccc(C(C)(C)C)cc2-c2ccccc2)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1]

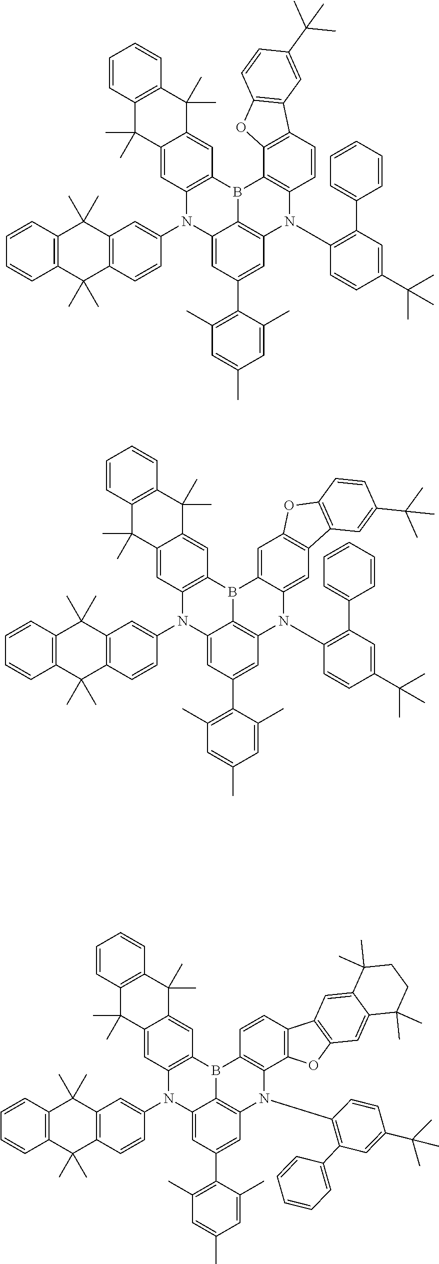 [SMILES: Cc1cc(C)c(-c2cc3c4c(c2)N(c2ccc(C(C)(C)C)cc2-c2ccccc2)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

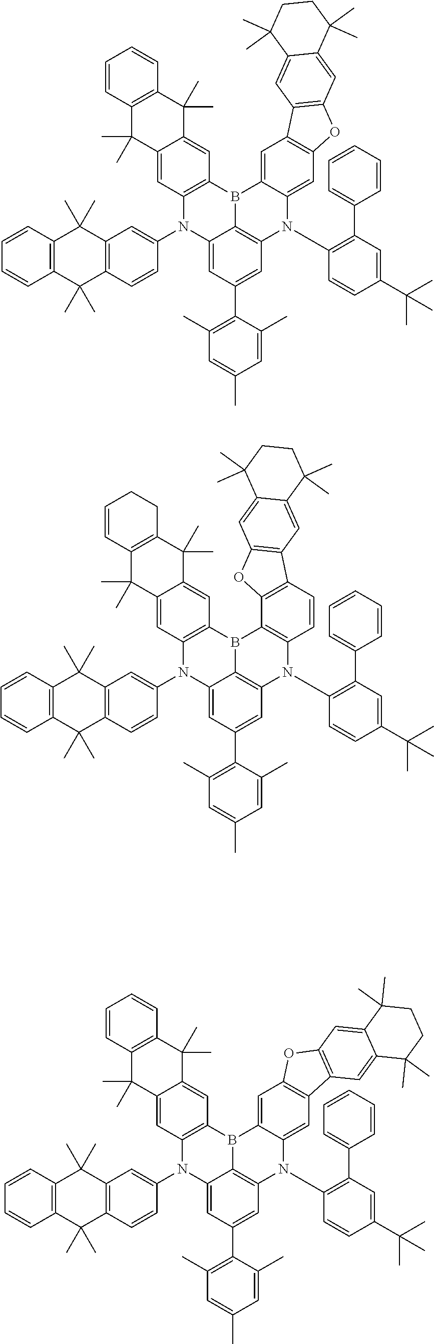

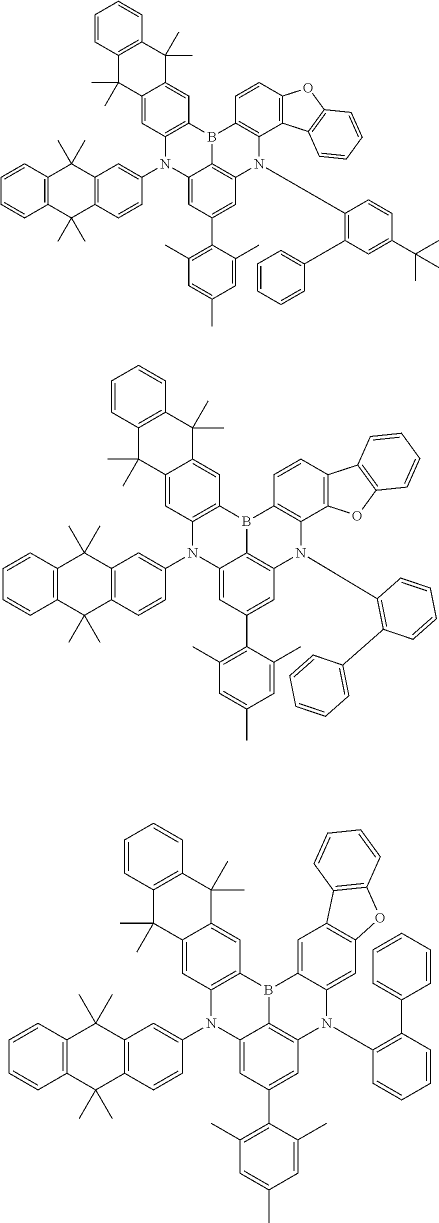 [SMILES: Cc1cc(C)c(-c2cc3c4c(c2)N(c2ccc(C(C)(C)C)cc2-c2ccccc2)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1]

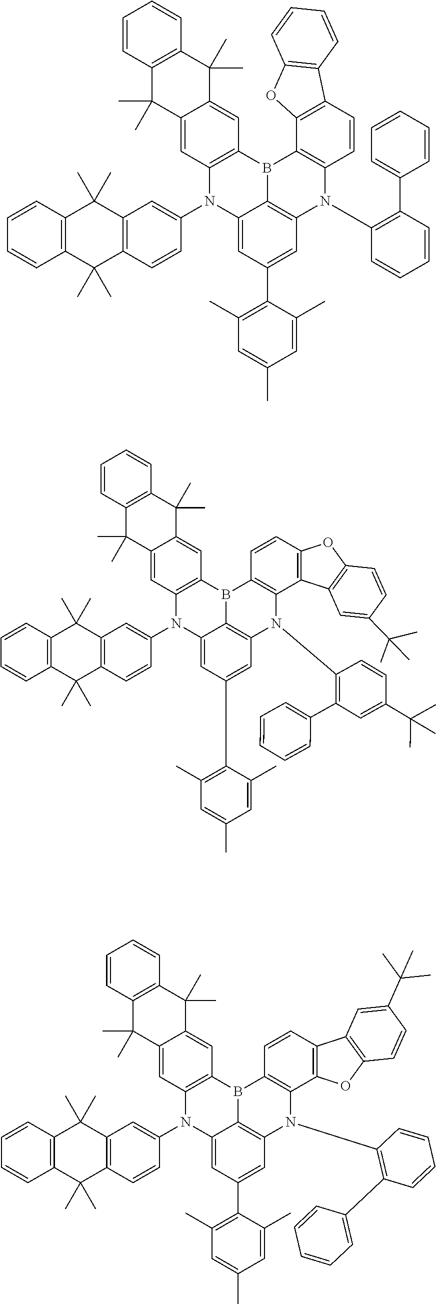 [SMILES: Cc1cc(C)c(-c2cc3c4c(c2)N(c2ccccc2-c2ccccc2)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1]

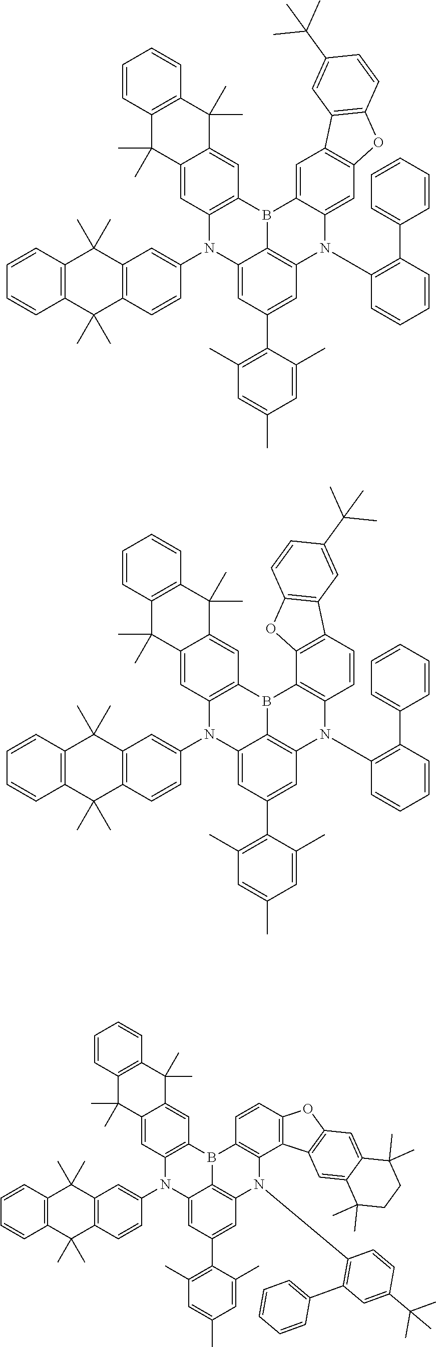 [SMILES: Cc1cc(C)c(-c2cc3c4c(c2)N(c2ccccc2-c2ccccc2)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1]

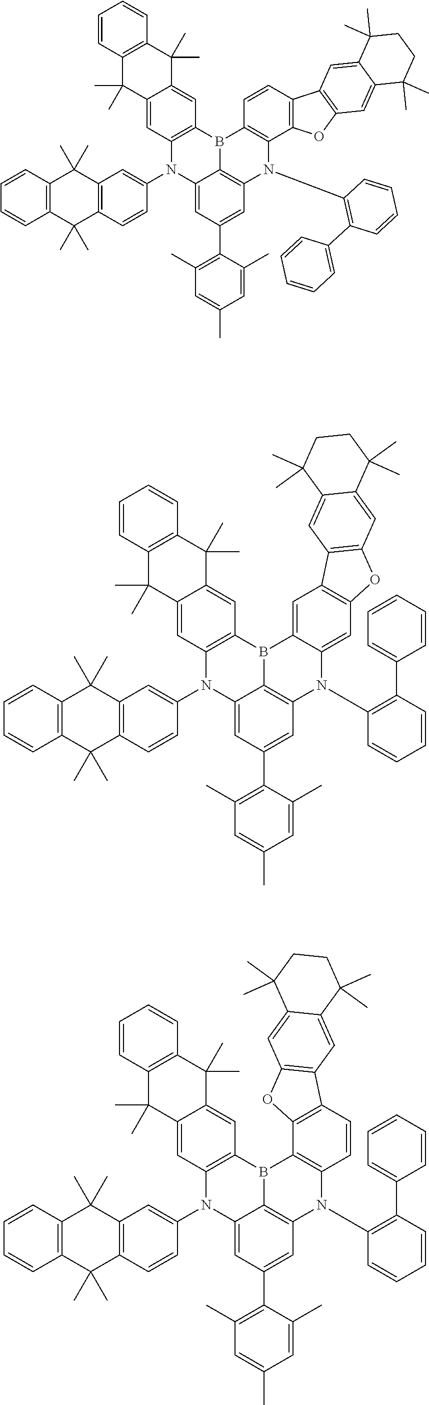 [SMILES: Cc1cc(C)c(-c2cc3c4c(c2)N(c2ccccc2-c2ccccc2)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5oc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1 ; Cc1cc(C)c(-c2cc3c4c(c2)N(c2ccccc2-c2ccccc2)c2ccc5c(oc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

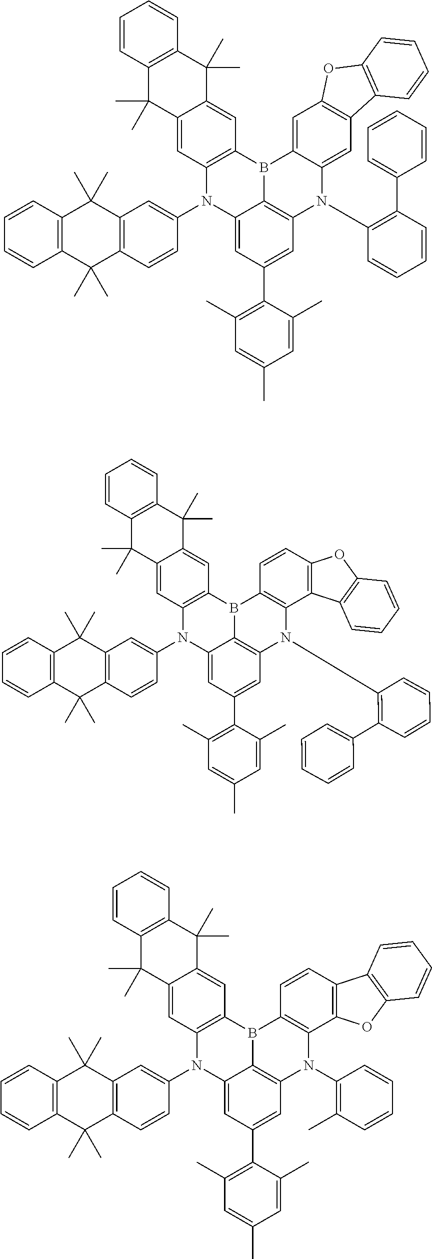 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1]

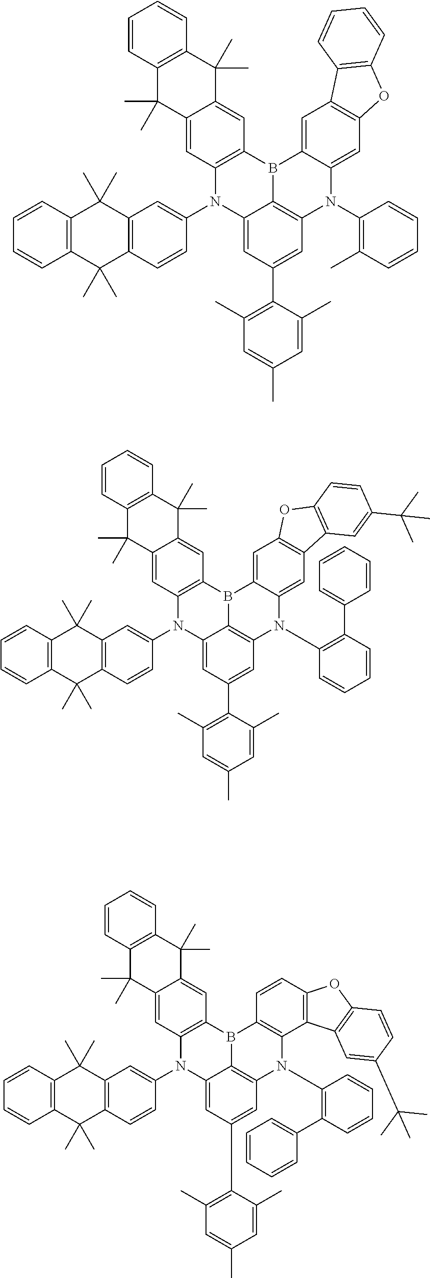 [SMILES: Cc1cc(C)c(-c2cc3c4c(c2)N(c2ccccc2C)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1 ; Cc1cc(C)c(-c2cc3c4c(c2)N(c2ccccc2-c2ccccc2)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1]

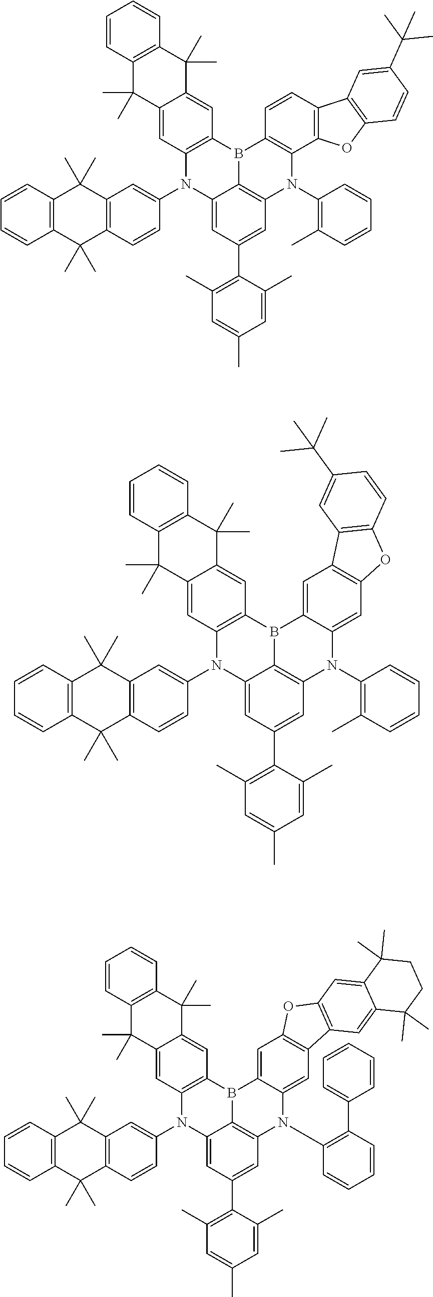 [SMILES: Cc1cc(C)c(-c2cc3c4c(c2)N(c2ccccc2C)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2cc3c(cc25)C(C)(C)CCC3(C)C)c(C)c1]

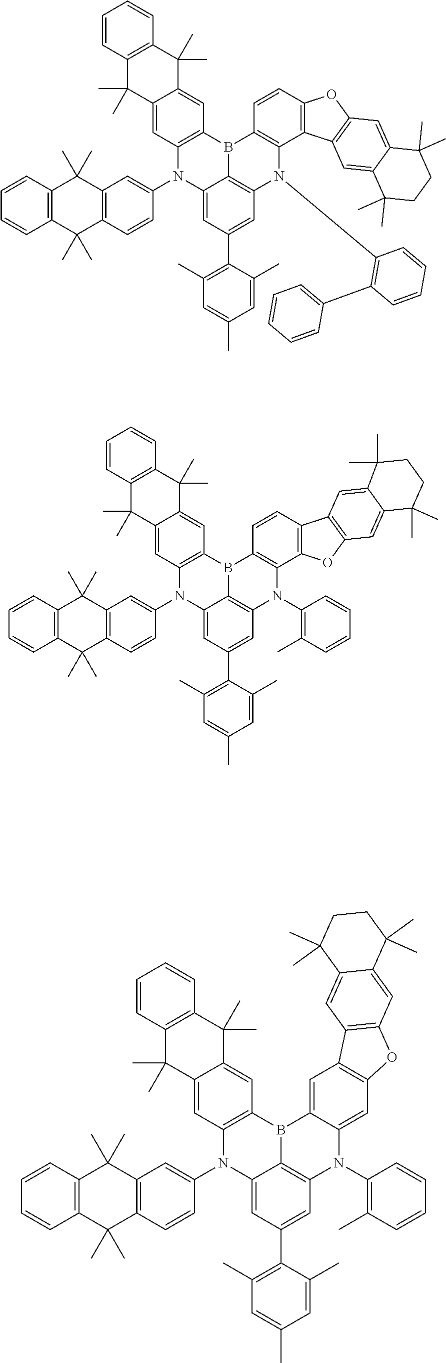 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5oc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

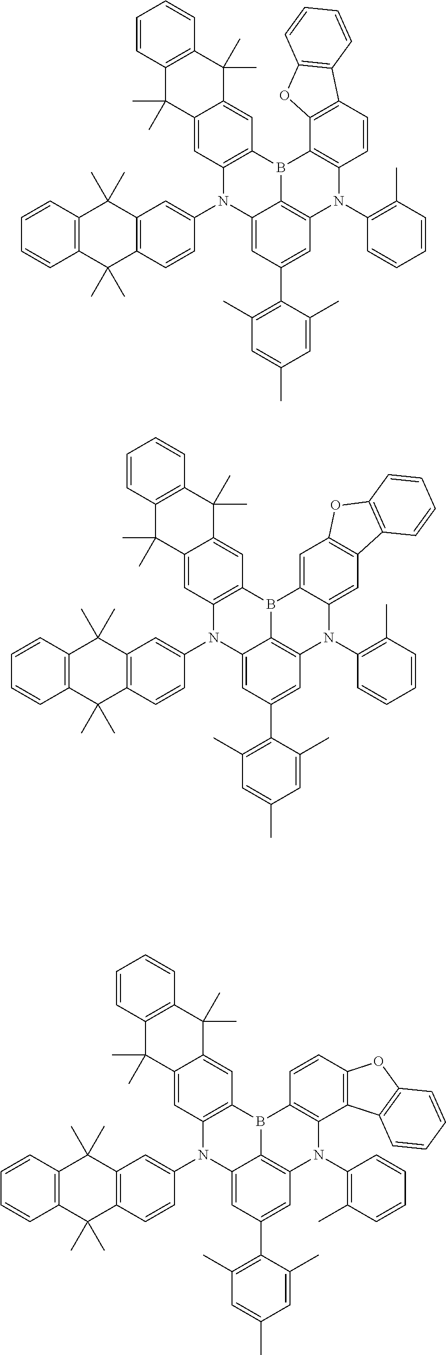 [SMILES: Cc1cc(C)c(-c2cc3c4c(c2)N(c2ccccc2C)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1]

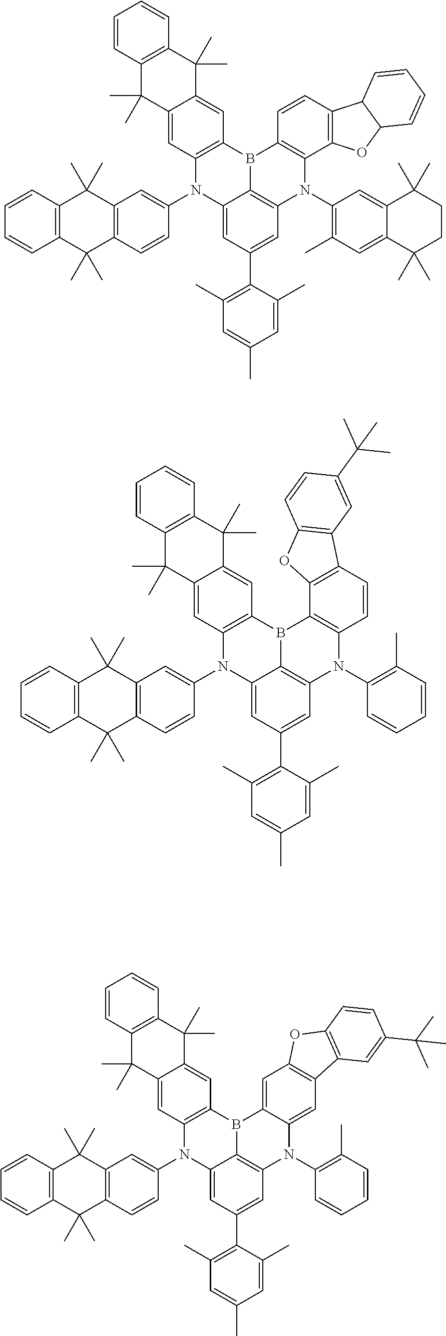 [SMILES: Cc1cc(C)c(-c2cc3c4c(c2)N(c2cc5c(cc2C)C(C)(C)CCC5(C)C)c2c(ccc5c2OC2C=CC=CC52)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1]

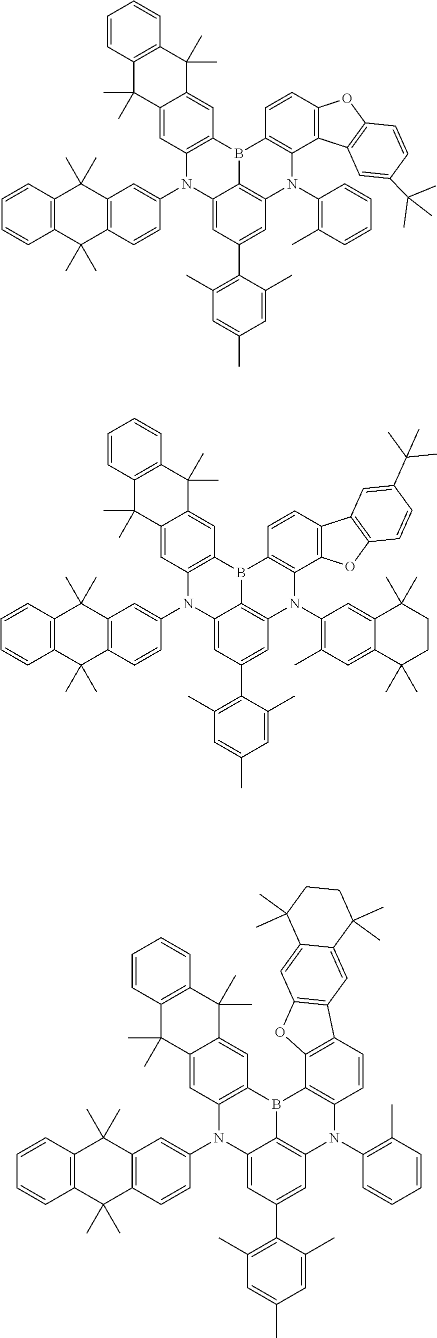 [SMILES: Cc1cc(C)c(-c2cc3c4c(c2)N(c2ccccc2C)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(oc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

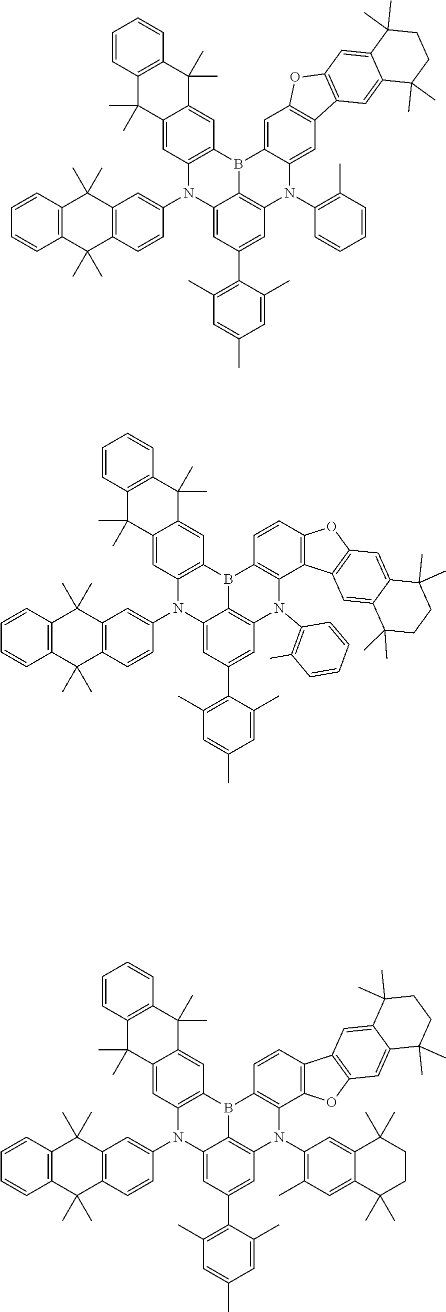 [SMILES: Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

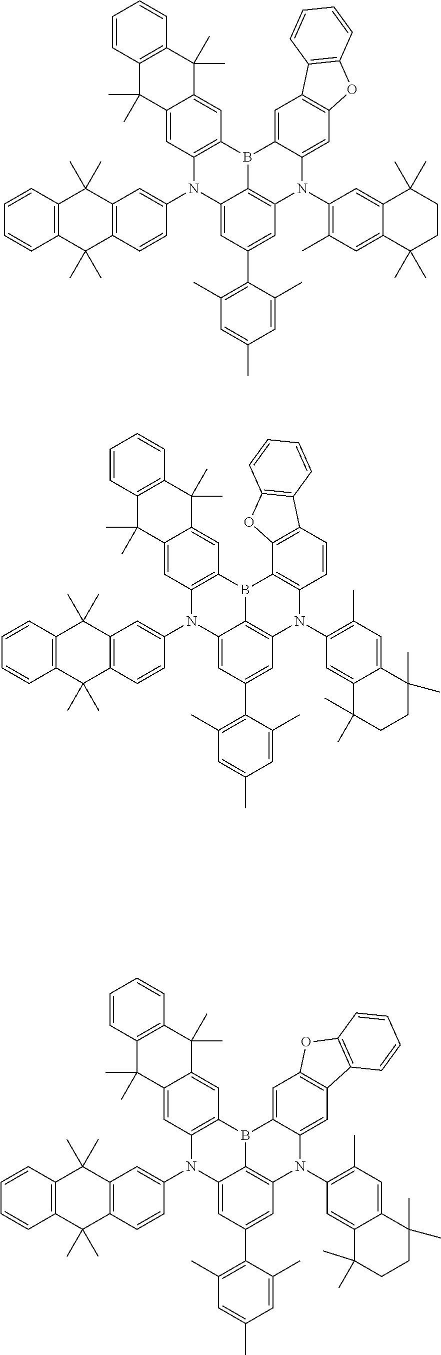 [SMILES: Cc1cc(C)c(-c2cc3c4c(c2)N(c2cc5c(cc2C)C(C)(C)CCC5(C)C)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1]

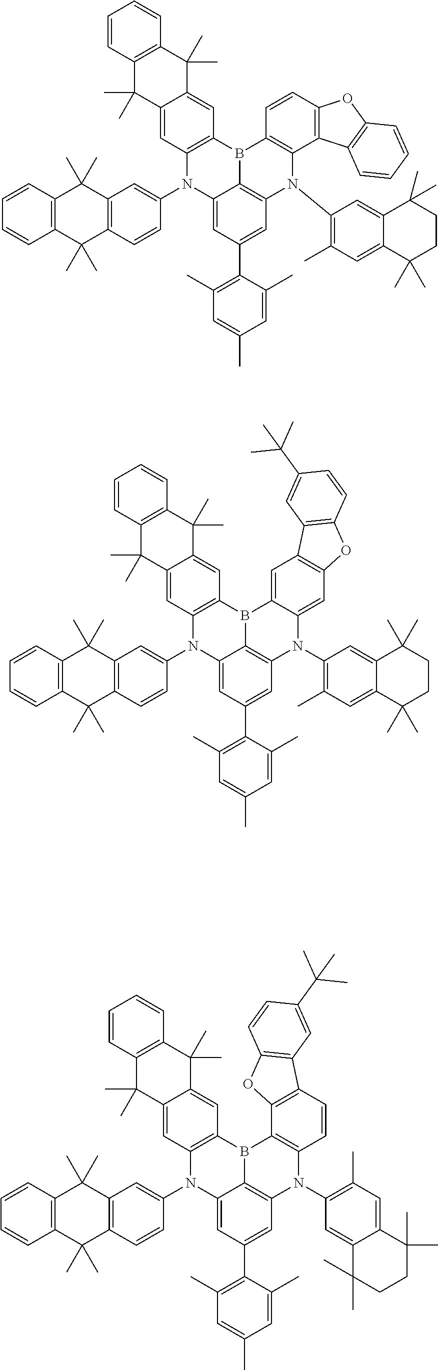 [SMILES: Cc1cc(C)c(-c2cc3c4c(c2)N(c2cc5c(cc2C)C(C)(C)CCC5(C)C)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1]

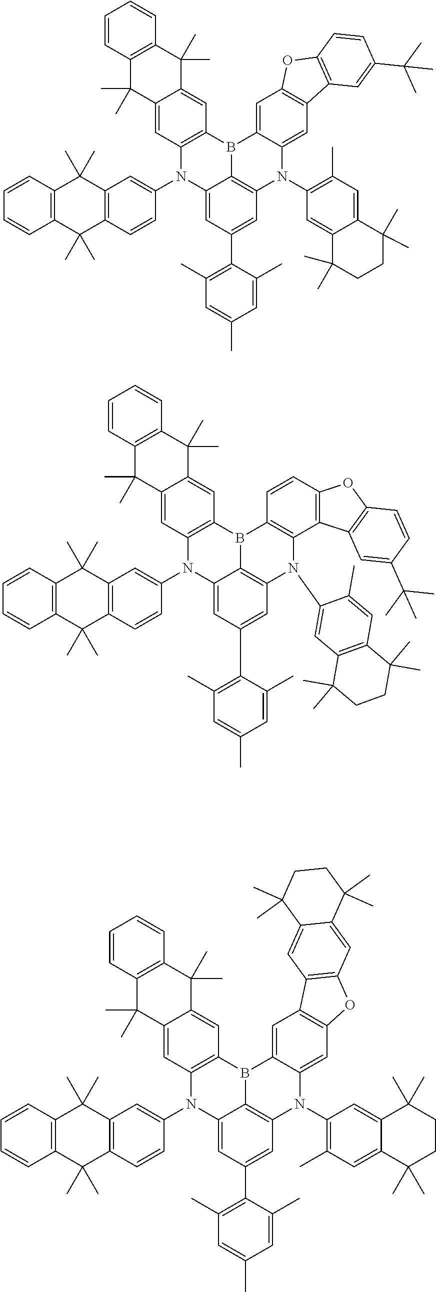 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

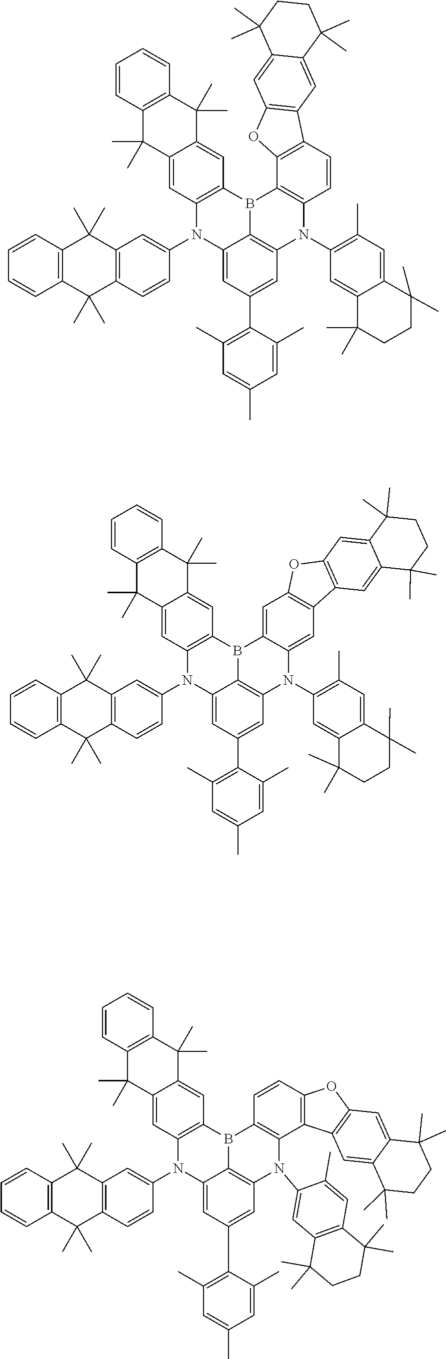

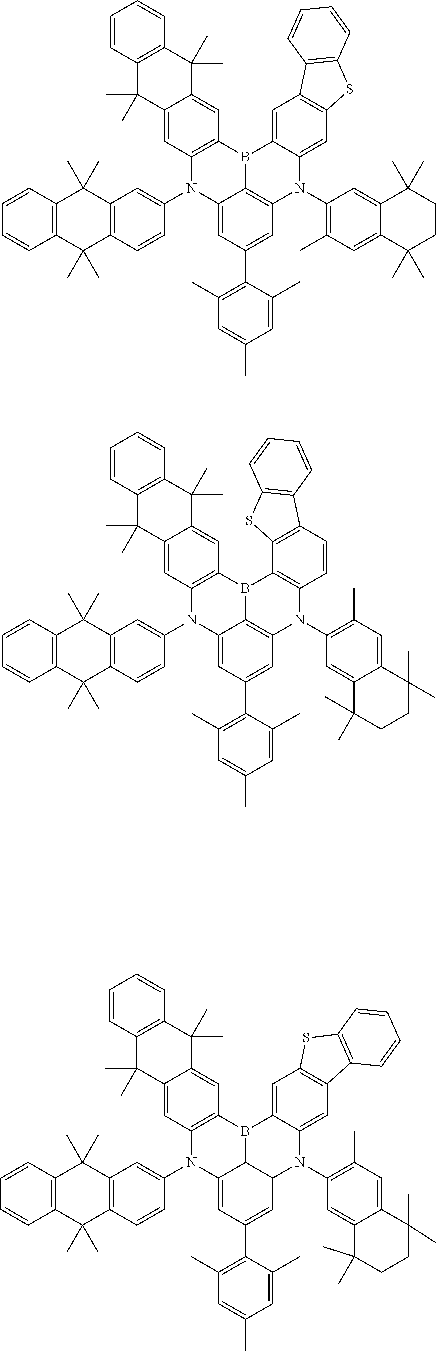 [SMILES: Cc1cc(C)c(-c2cc3c4c(c2)N(c2cc5c(cc2C)C(C)(C)CCC5(C)C)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(C2=CC3C4B(c5cc6c(cc5N(c5ccc7c(c5)C(C)(C)c5ccccc5C7(C)C)C4=C2)C(C)(C)c2ccccc2C6(C)C)c2cc4sc5ccccc5c4cc2N3c2cc3c(cc2C)C(C)(C)CCC3(C)C)c(C)c1]

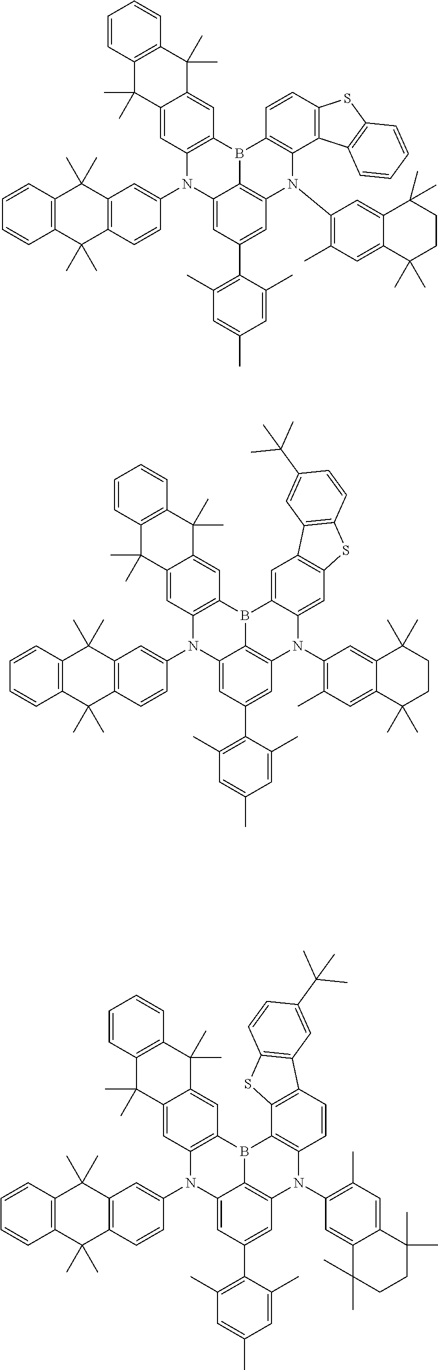 [SMILES: Cc1cc(C)c(-c2cc3c4c(c2)N(c2cc5c(cc2C)C(C)(C)CCC5(C)C)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1]

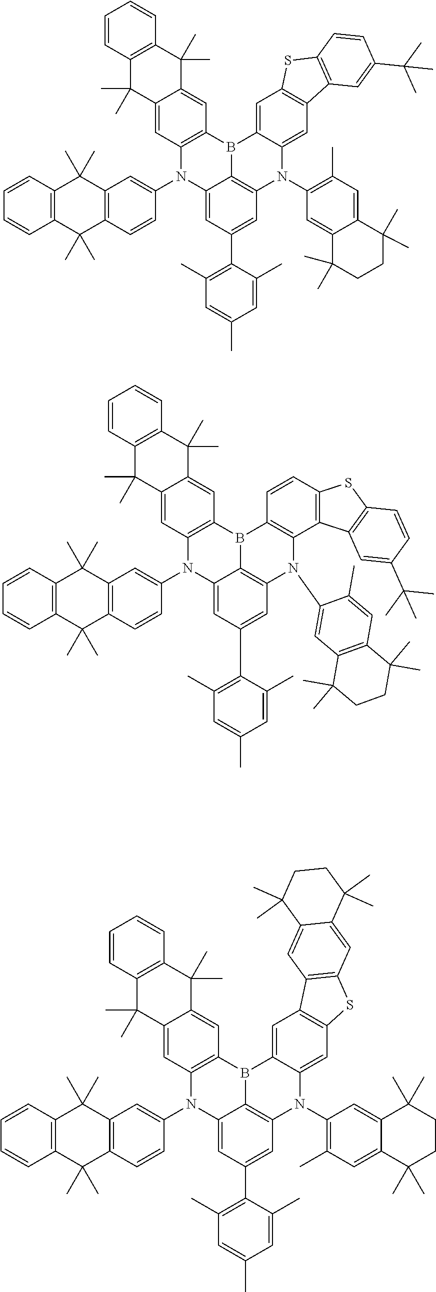 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5sc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

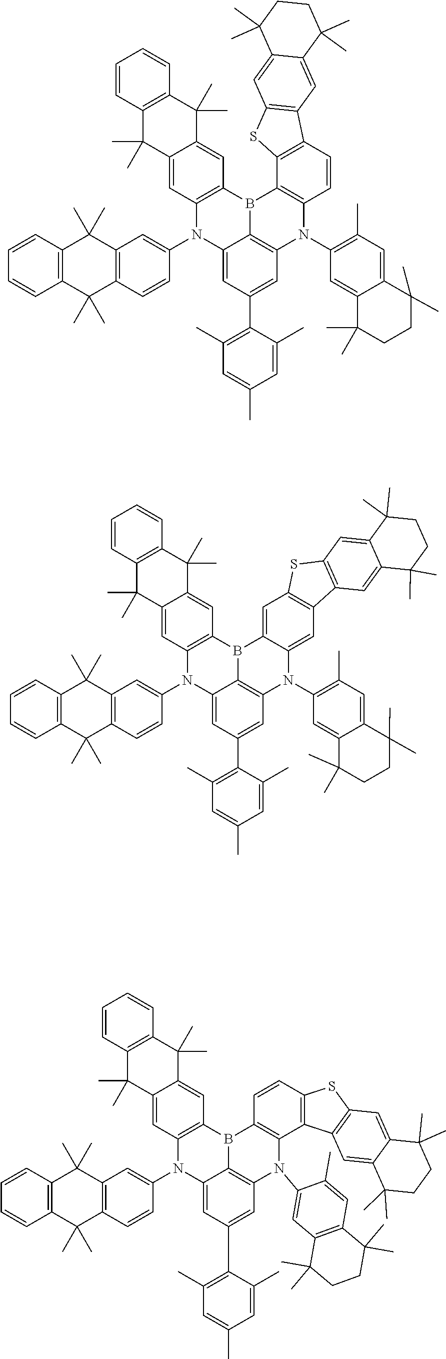

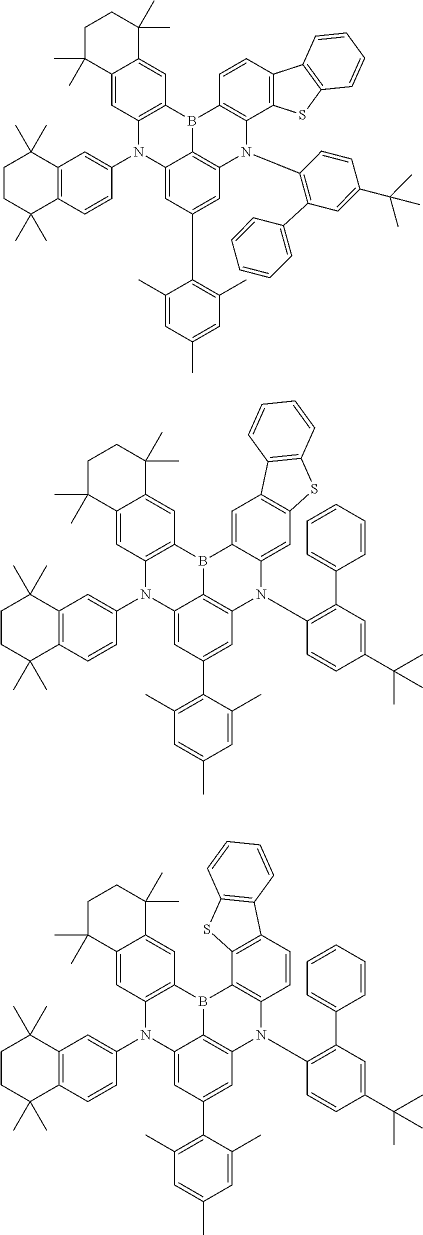 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2ccc3c(c2)C(C)(C)CCC3(C)C)C(C)(C)CCC4(C)C)c(C)c1]

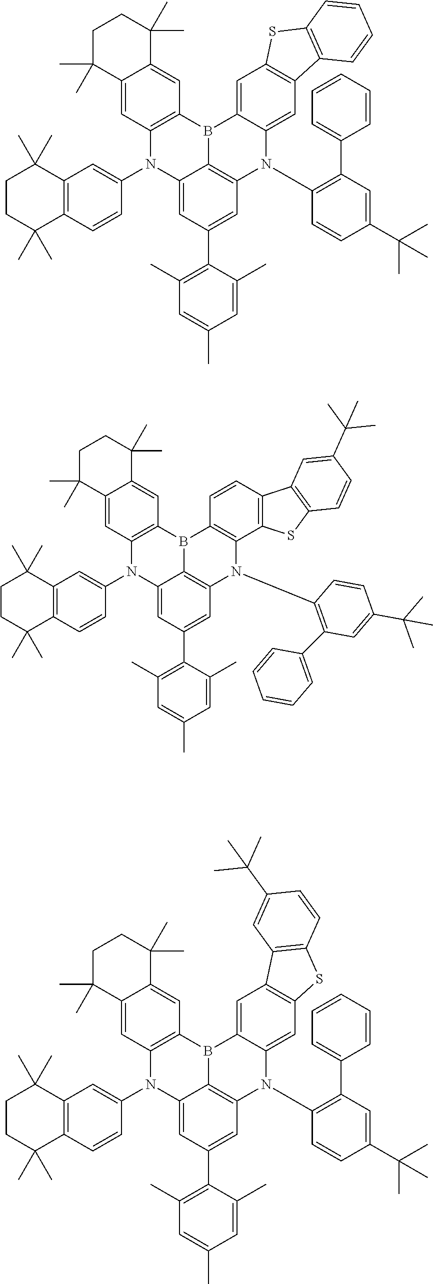 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1]

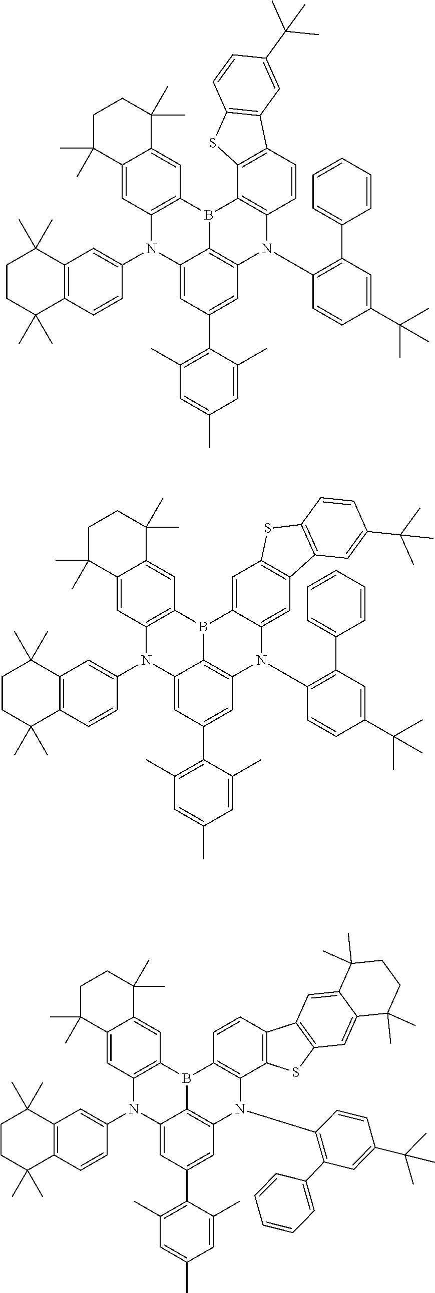 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1]

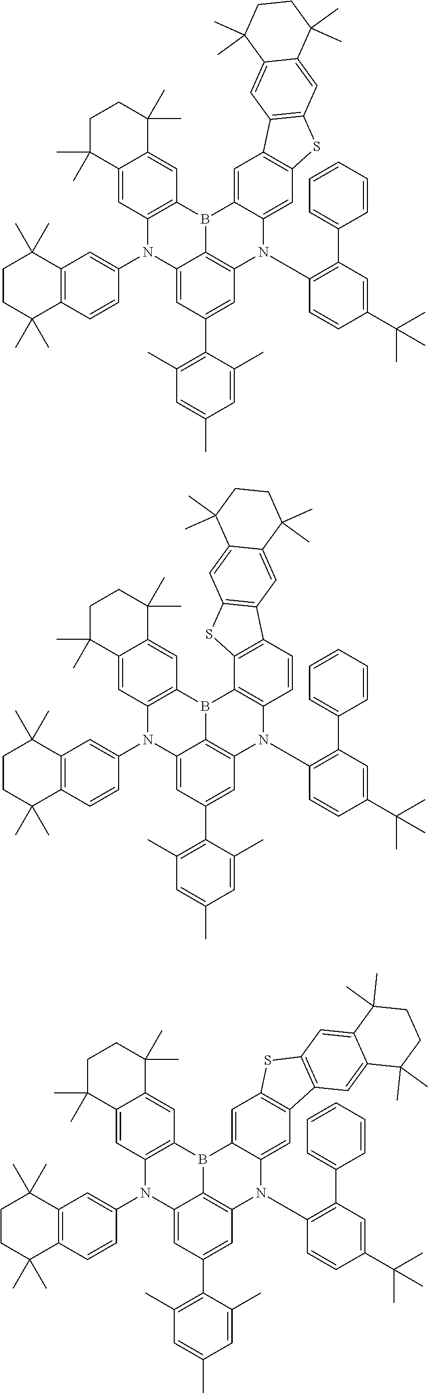 [SMILES: Cc1cc(C)c(-c2cc3c4c(c2)N(c2ccc(C(C)(C)C)cc2-c2ccccc2)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1 ; Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1]

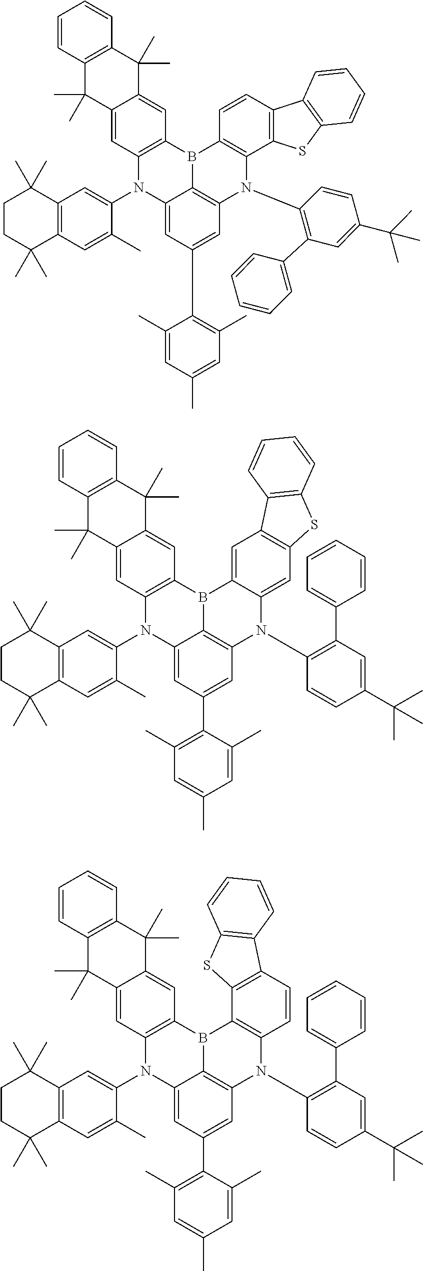 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2cc3c(cc2C)C(C)(C)CCC3(C)C)C(C)(C)c2ccccc2C4(C)C)c(C)c1]

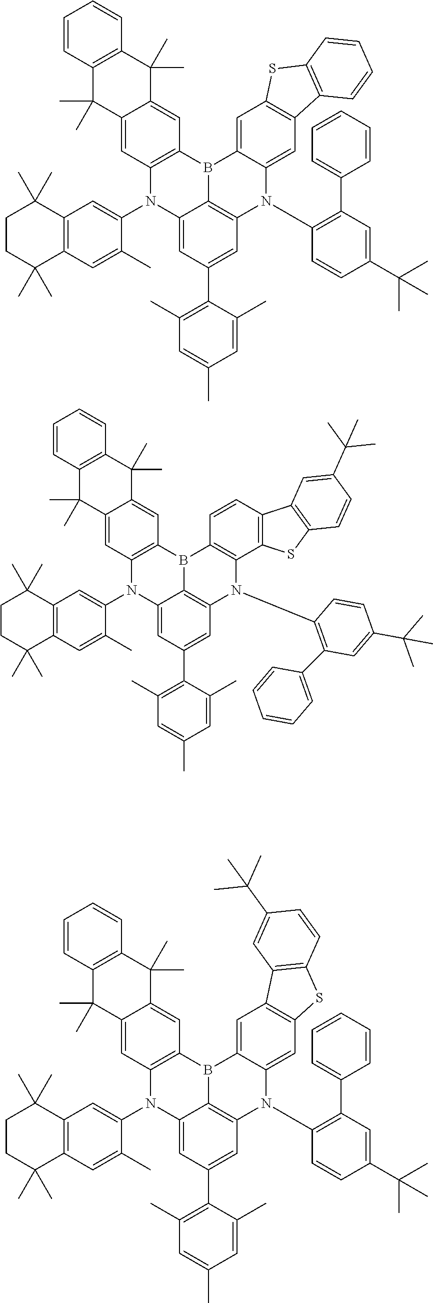 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1]

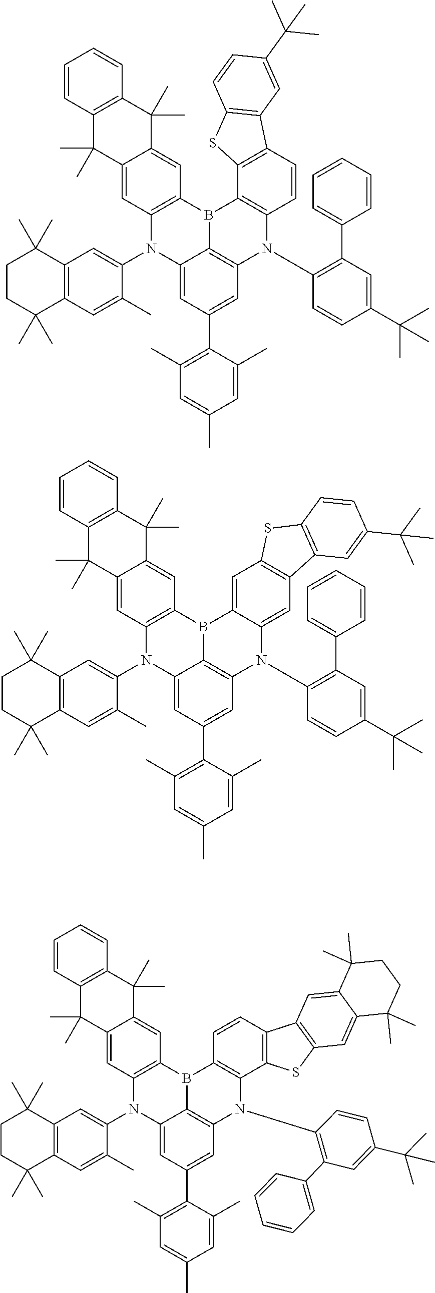 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1]

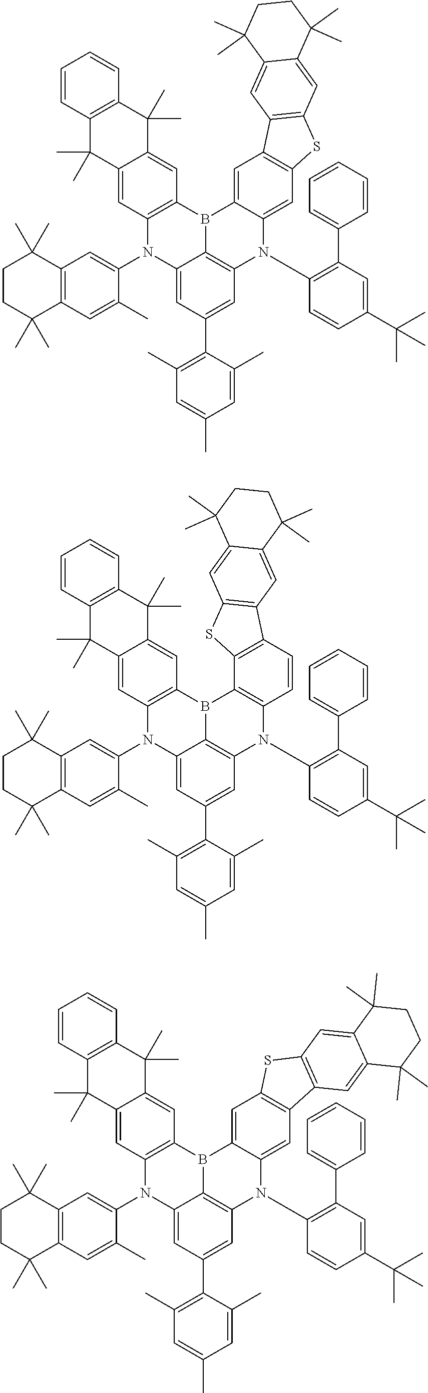 [SMILES: Cc1cc(C)c(-c2cc3c4c(c2)N(c2ccc(C(C)(C)C)cc2-c2ccccc2)c2cc5sc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1 ; Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)sc2cc3c(cc25)C(C)(C)CCC3(C)C)c(C)c1]

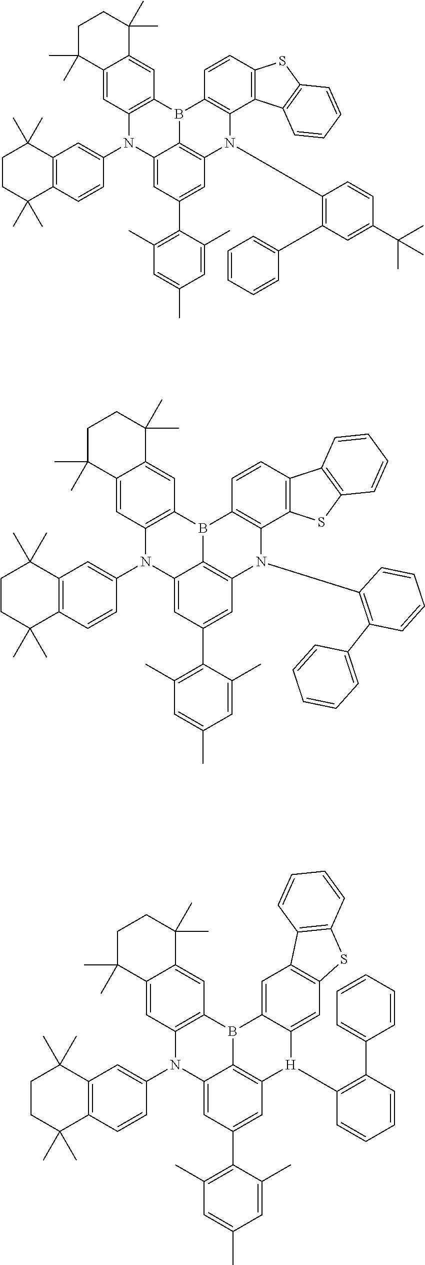

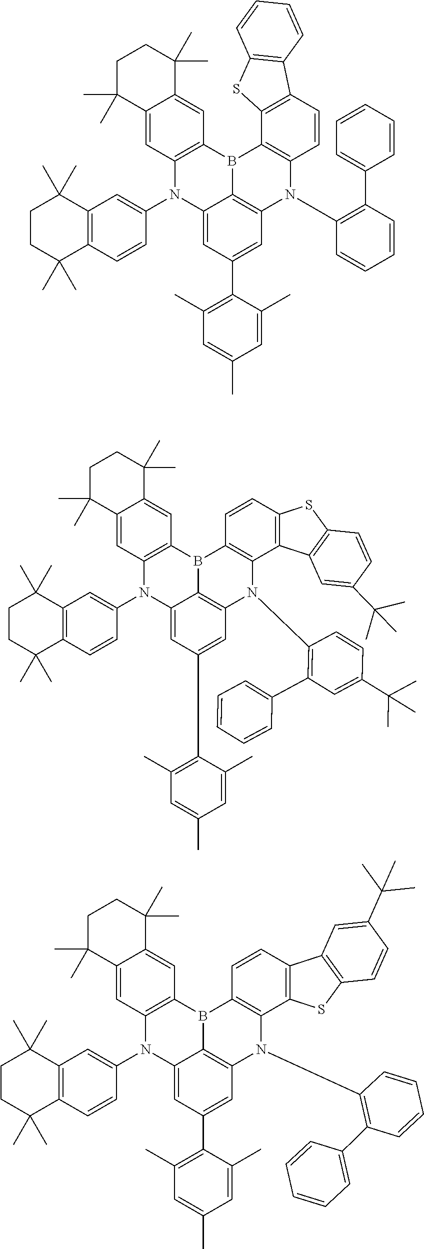 [SMILES: Cc1cc(C)c(-c2cc3c4c(c2)N(c2ccccc2-c2ccccc2)c2ccc5c(sc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1]

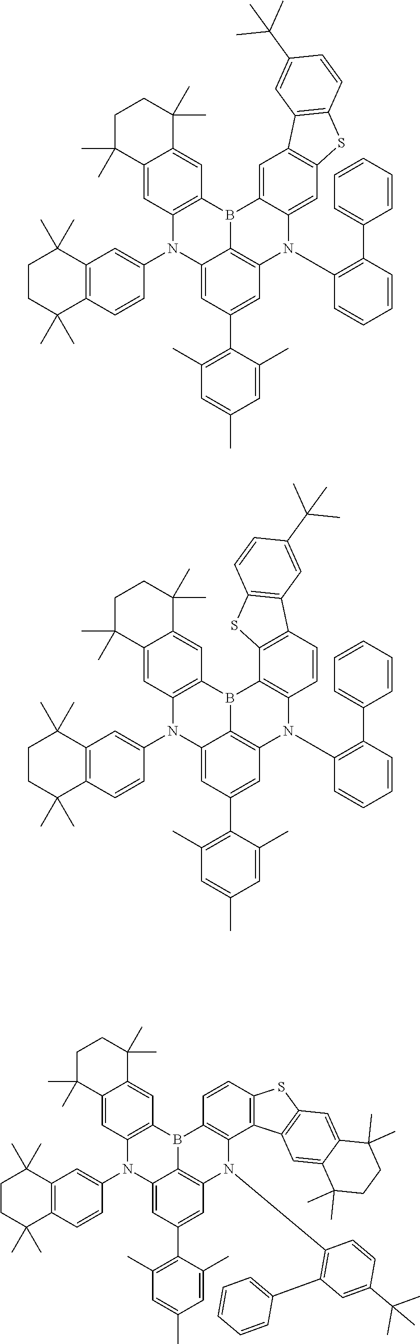 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

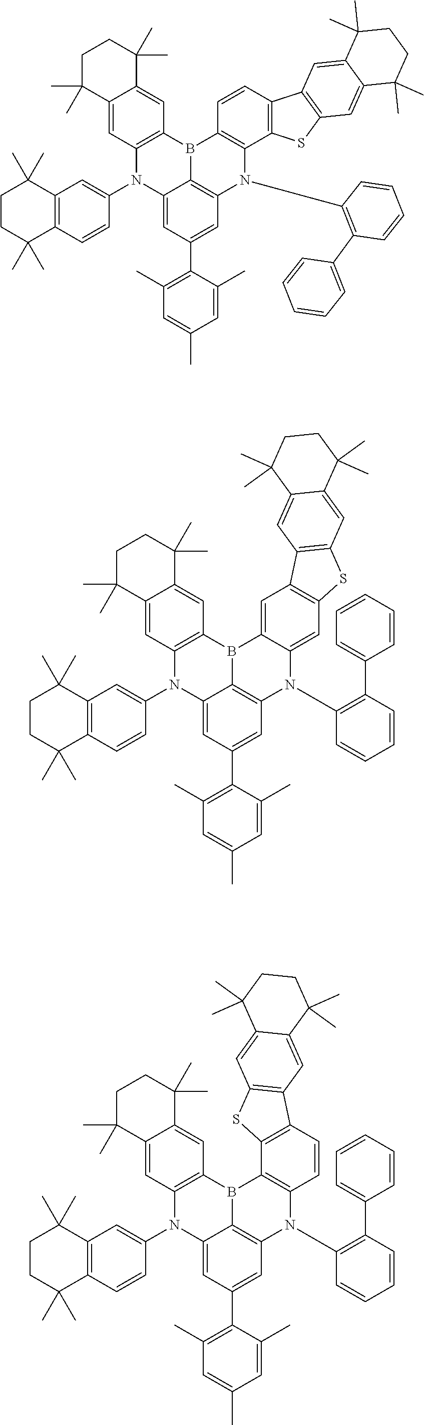 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1]

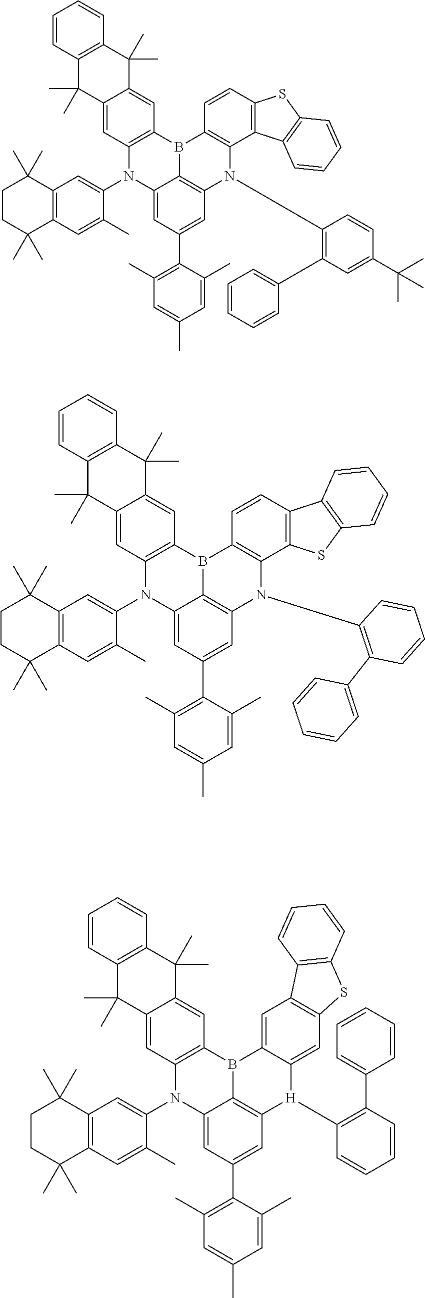

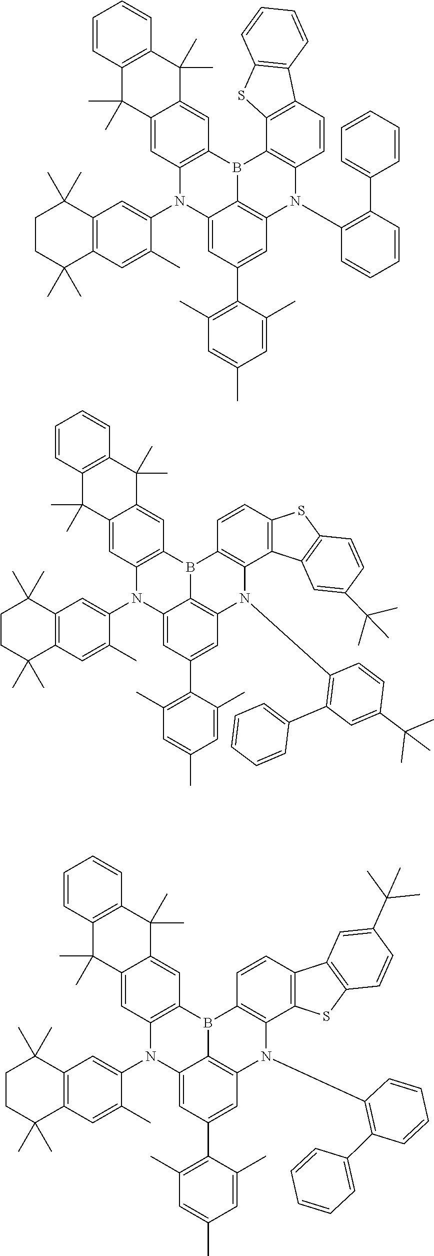 [SMILES: Cc1cc(C)c(-c2cc3c4c(c2)N(c2ccccc2-c2ccccc2)c2ccc5c(sc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1]

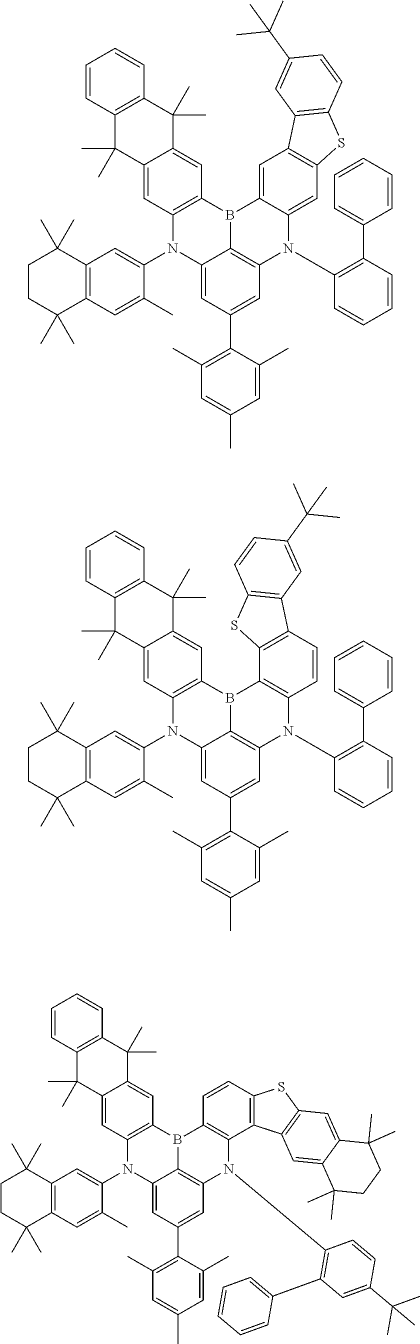 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1]

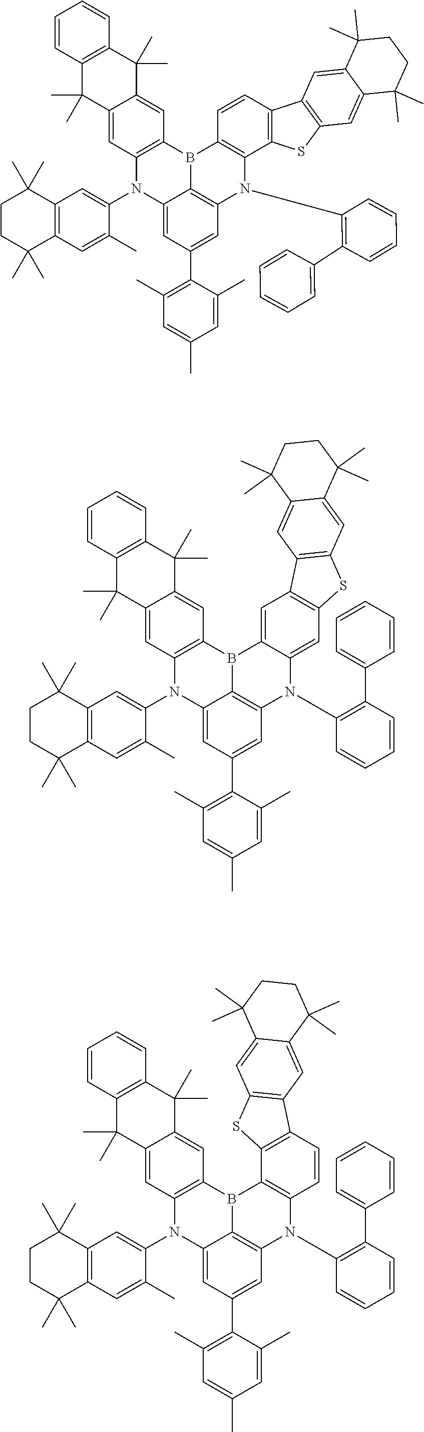 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1]

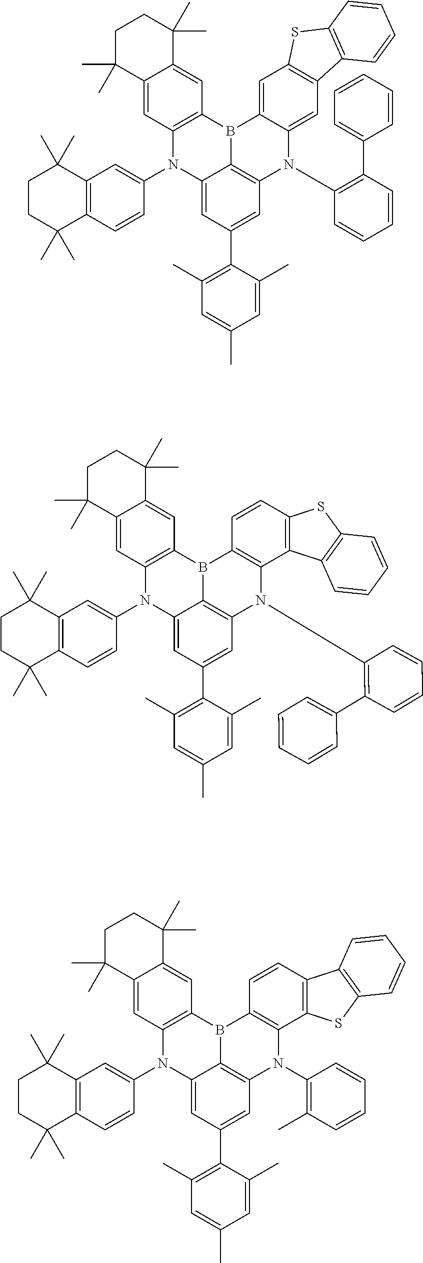 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2sc2ccccc25)B4c2cc4c(cc2N3c2ccc3c(c2)C(C)(C)CCC3(C)C)C(C)(C)CCC4(C)C)c(C)c1]

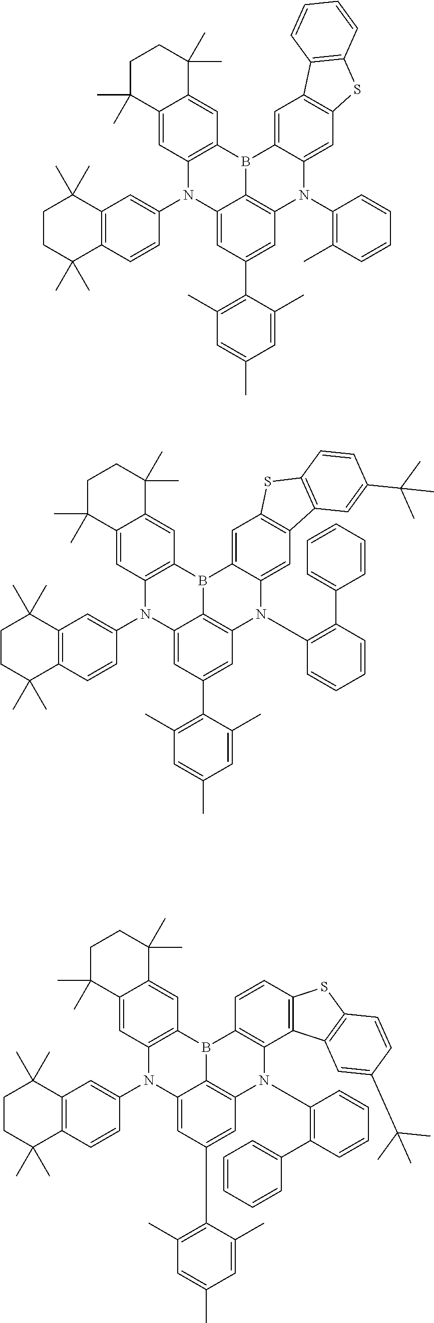 [SMILES: Cc1cc(C)c(-c2cc3c4c(c2)N(c2ccccc2C)c2cc5sc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1 ; Cc1cc(C)c(-c2cc3c4c(c2)N(c2ccccc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1]

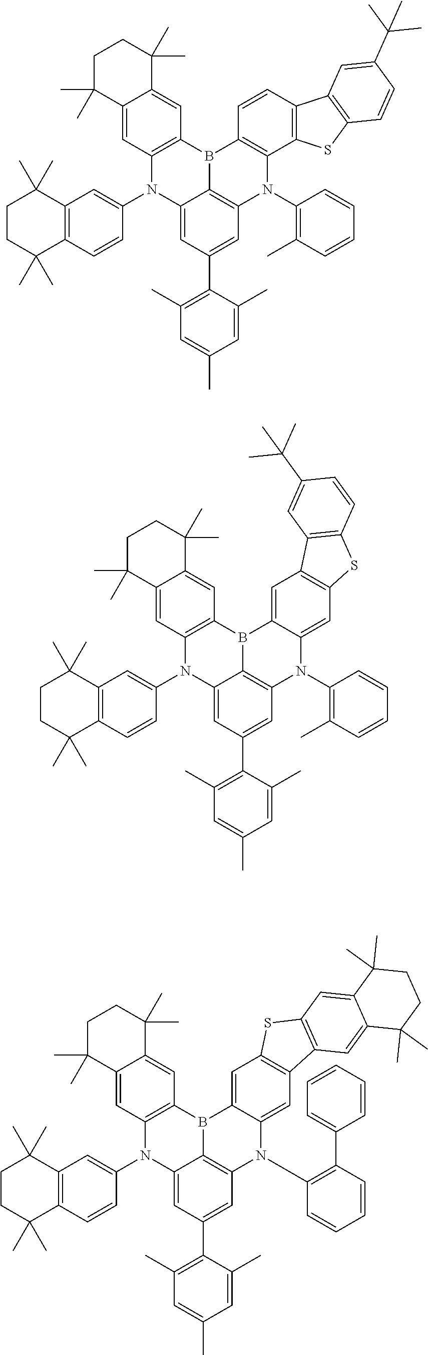 [SMILES: Cc1cc(C)c(-c2cc3c4c(c2)N(c2ccccc2C)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1]

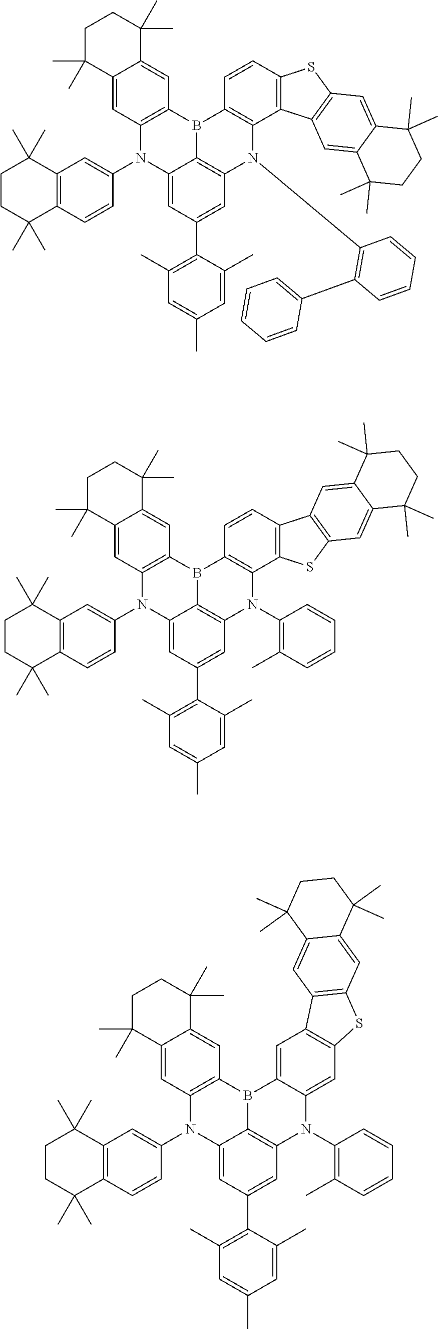 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

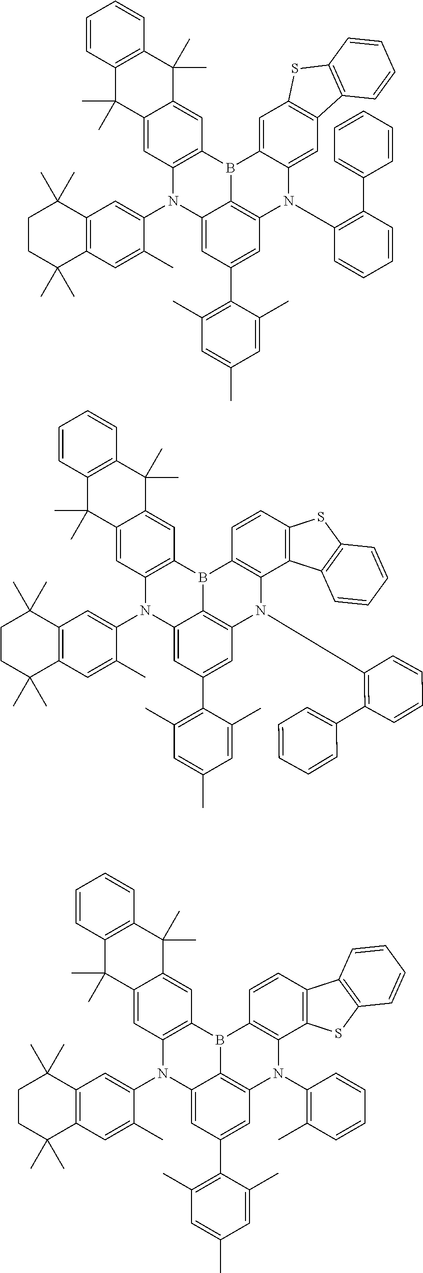 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2sc2ccccc25)B4c2cc4c(cc2N3c2cc3c(cc2C)C(C)(C)CCC3(C)C)C(C)(C)c2ccccc2C4(C)C)c(C)c1]

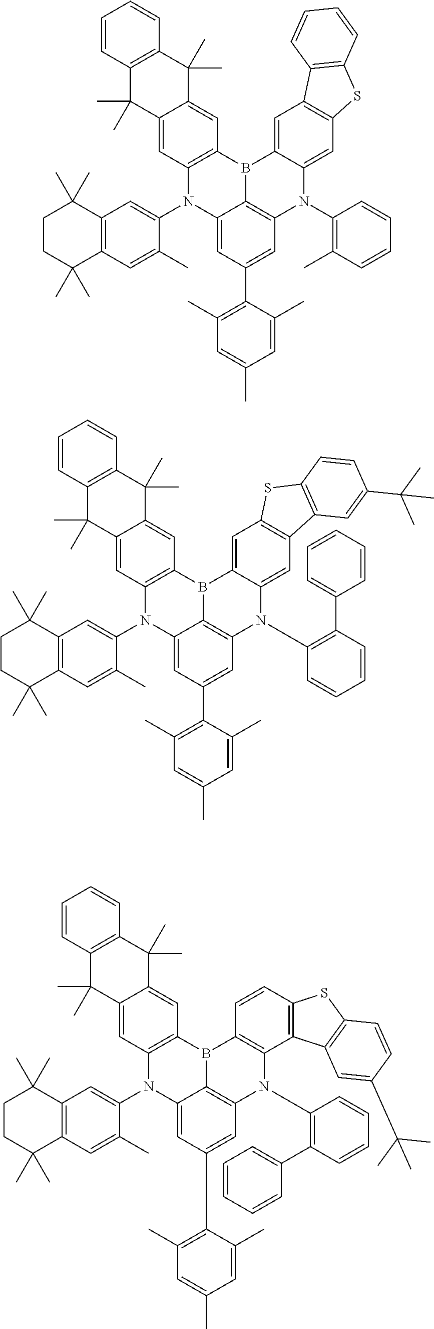 [SMILES: Cc1cc(C)c(-c2cc3c4c(c2)N(c2ccccc2C)c2cc5sc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)sc2ccc(C(C)(C)C)cc25)c(C)c1 ; Cc1cc(C)c(-c2cc3c4c(c2)N(c2ccccc2-c2ccccc2)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1]

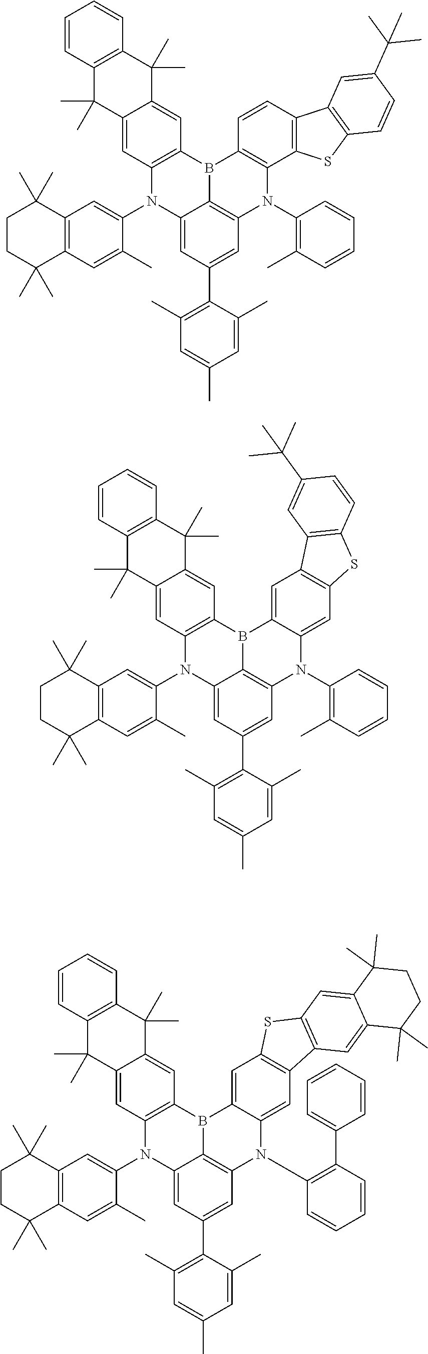 [SMILES: Cc1cc(C)c(-c2cc3c4c(c2)N(c2ccccc2C)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)sc2cc3c(cc25)C(C)(C)CCC3(C)C)c(C)c1]

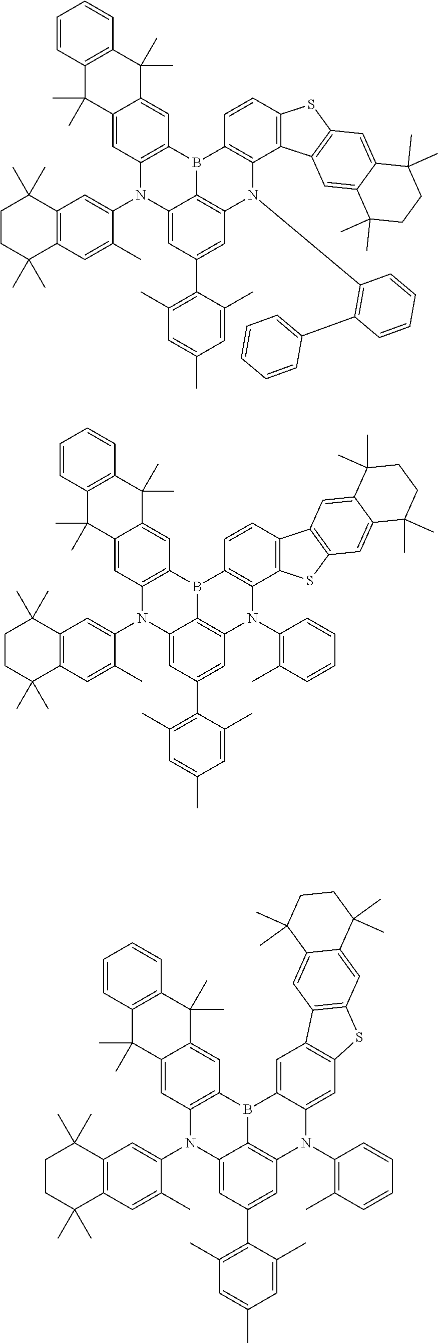 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5sc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1]

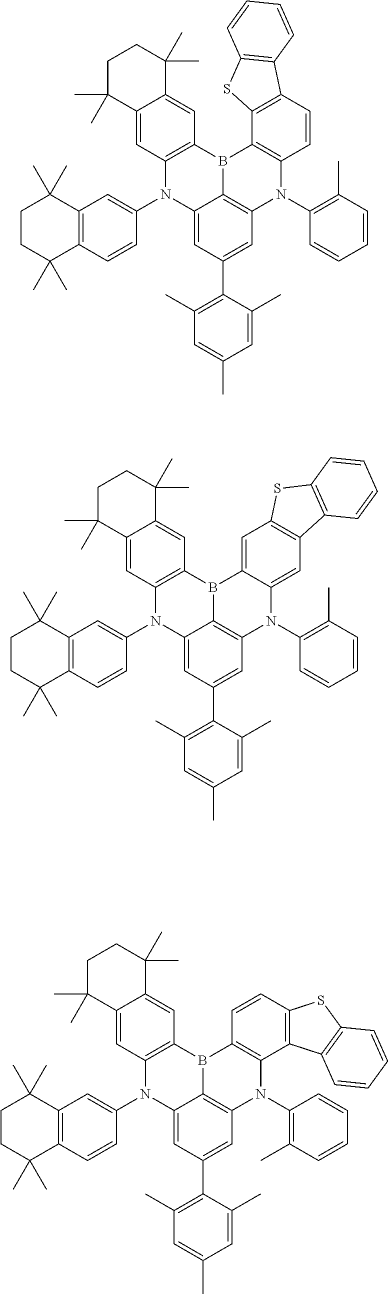 [SMILES: Cc1cc(C)c(-c2cc3c4c(c2)N(c2ccccc2C)c2ccc5c(sc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2ccc3c(c2)C(C)(C)CCC3(C)C)C(C)(C)CCC4(C)C)c(C)c1]

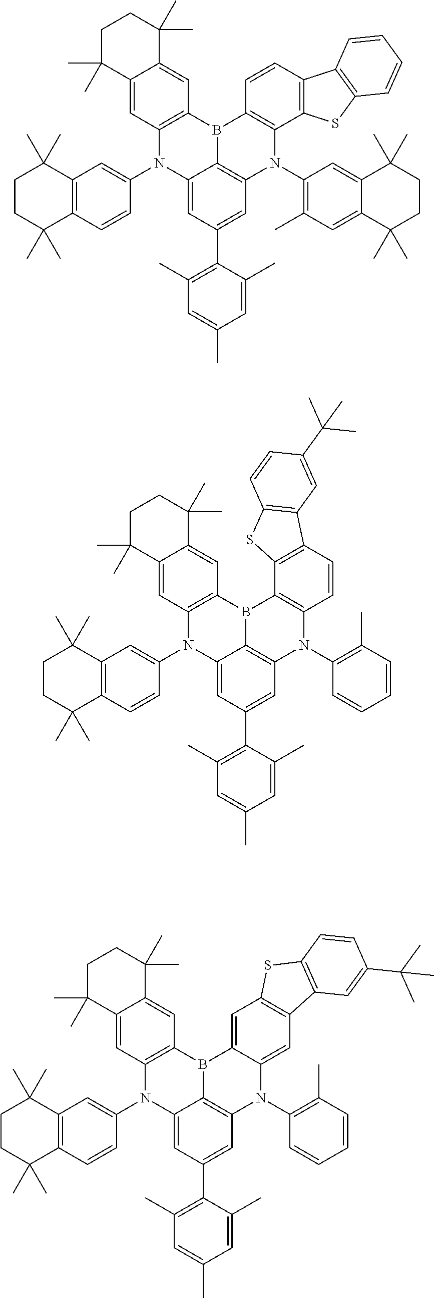 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1]

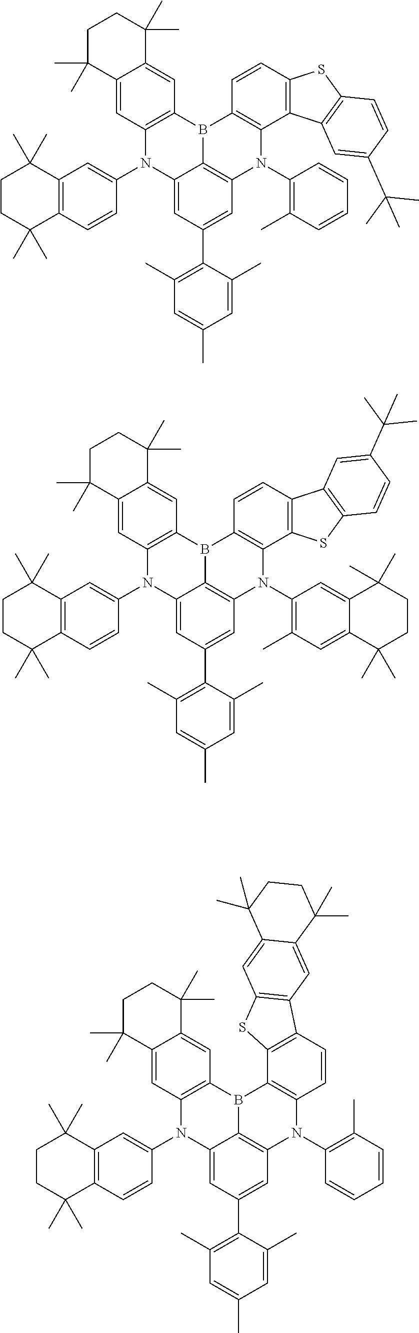 [SMILES: Cc1cc(C)c(-c2cc3c4c(c2)N(c2ccccc2C)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1]

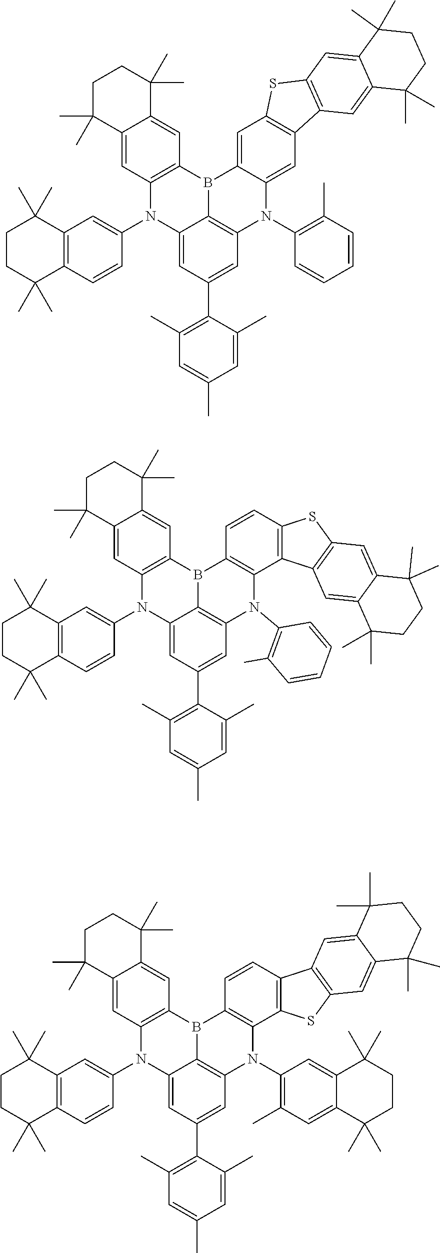 [SMILES: Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1 ; Cc1cc(C)c(-c2cc3c4c(c2)N(c2ccccc2C)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1]

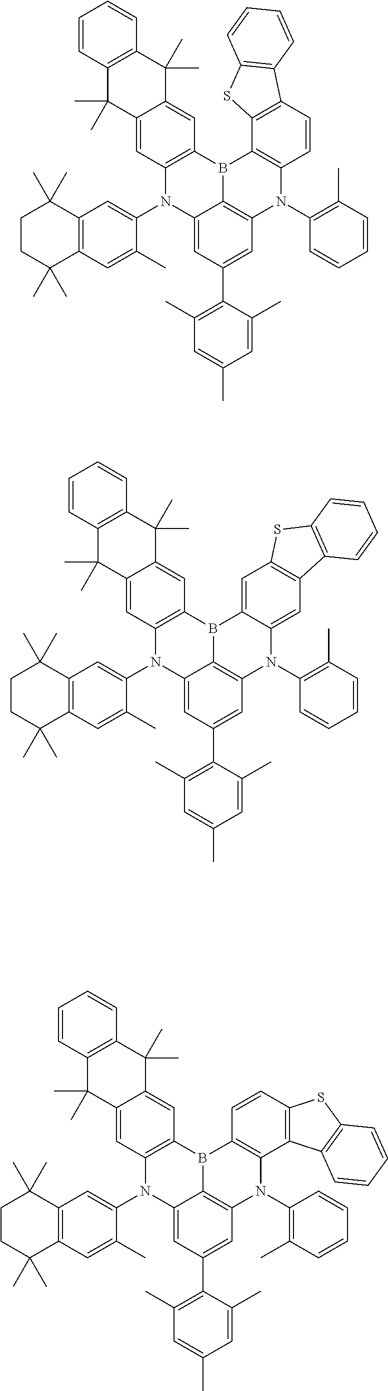 [SMILES: Cc1cc(C)c(-c2cc3c4c(c2)N(c2ccccc2C)c2ccc5c(sc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2cc3c(cc2C)C(C)(C)CCC3(C)C)C(C)(C)c2ccccc2C4(C)C)c(C)c1]

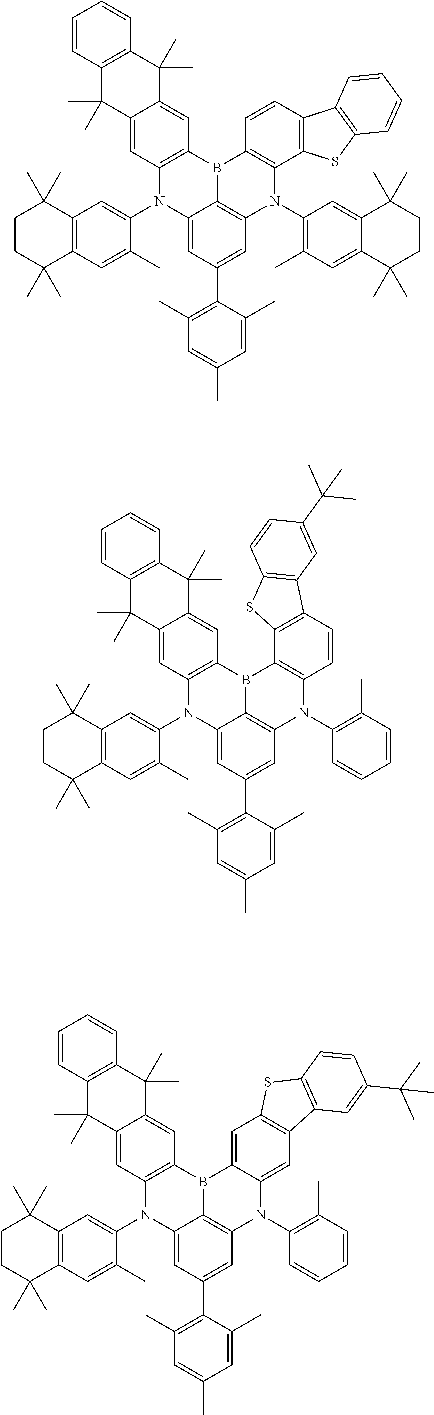 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)sc2ccc(C(C)(C)C)cc25)c(C)c1]

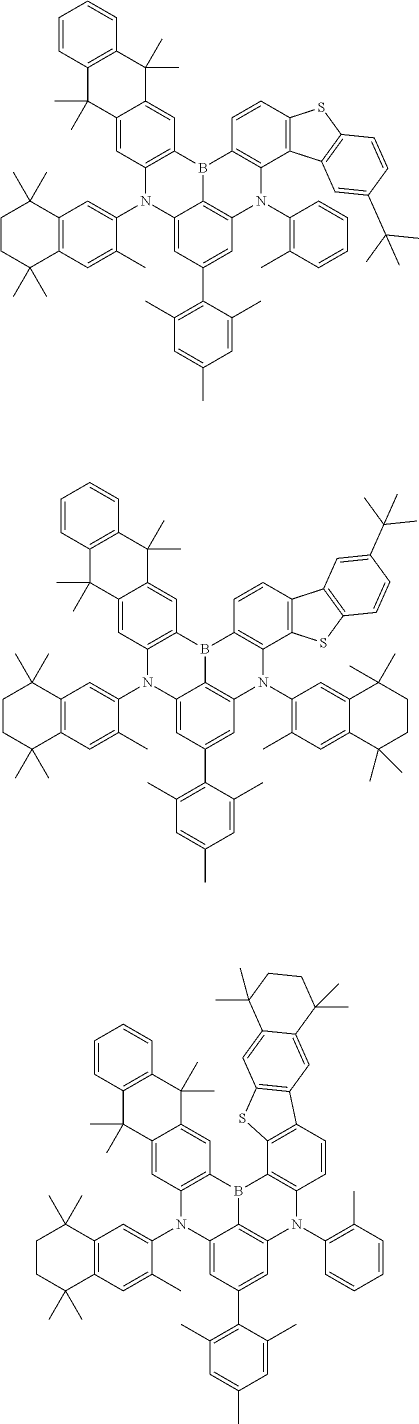 [SMILES: Cc1cc(C)c(-c2cc3c4c(c2)N(c2ccccc2C)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(sc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1]

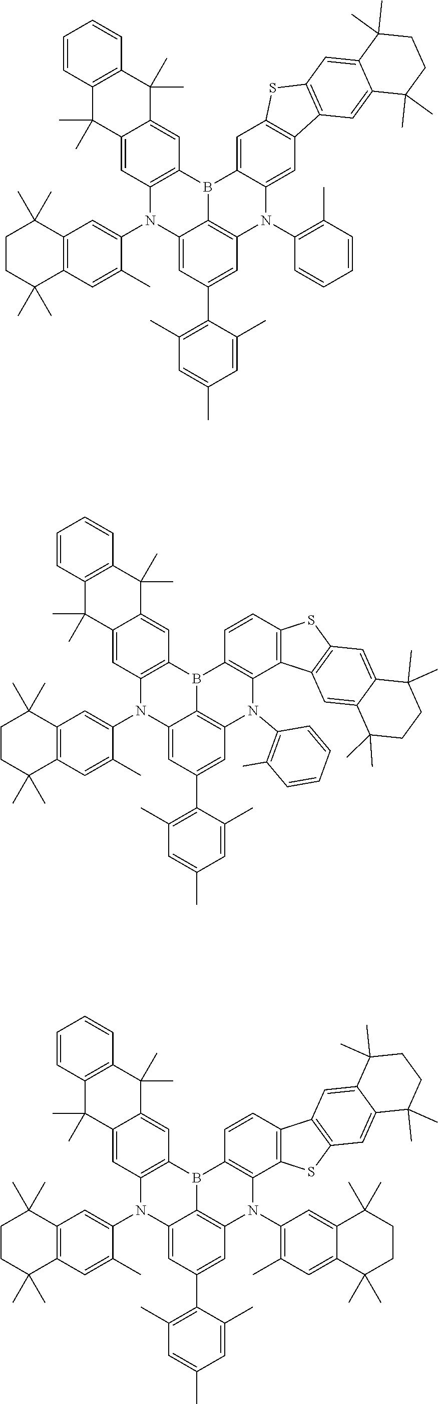 [SMILES: Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)sc2cc3c(cc25)C(C)(C)CCC3(C)C)c(C)c1 ; Cc1cc(C)c(-c2cc3c4c(c2)N(c2ccccc2C)c2c(ccc5sc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1]

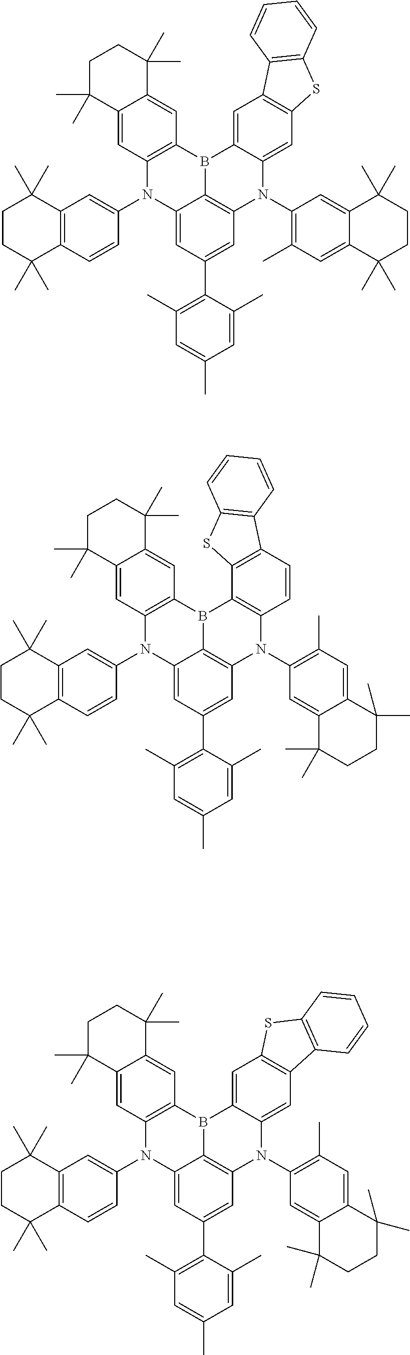 [SMILES: Cc1cc(C)c(-c2cc3c4c(c2)N(c2cc5c(cc2C)C(C)(C)CCC5(C)C)c2cc5sc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccc5c(sc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2ccccc25)c(C)c1]

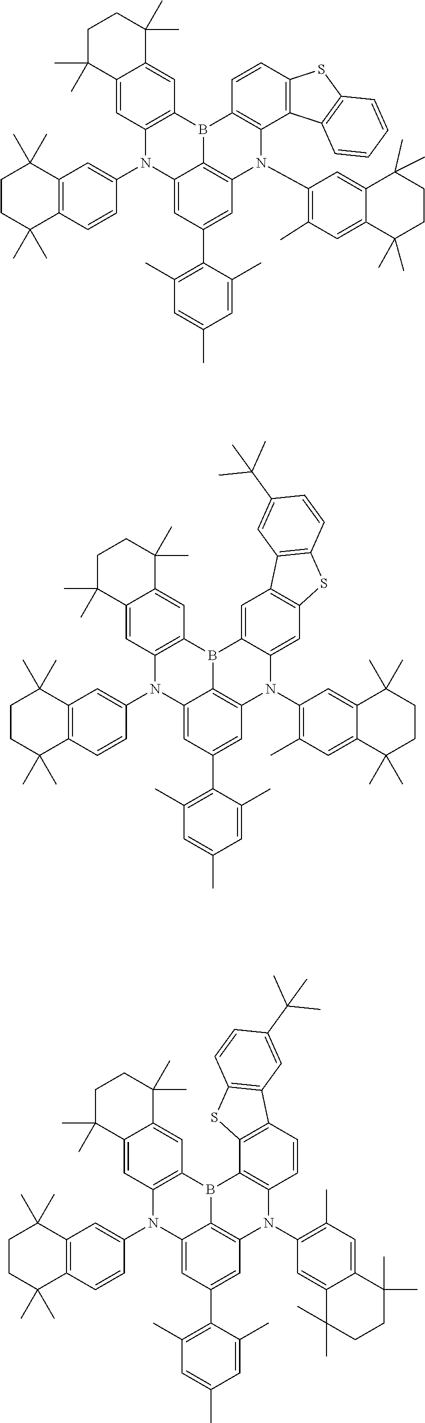 [SMILES: Cc1cc(C)c(-c2cc3c4c(c2)N(c2cc5c(cc2C)C(C)(C)CCC5(C)C)c2c(ccc5sc6ccccc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1]

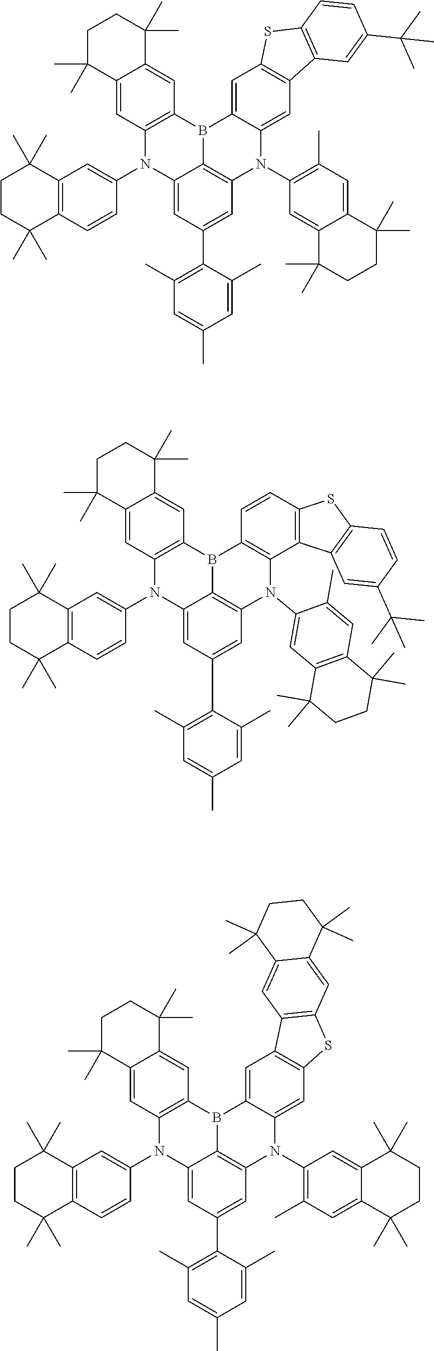 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

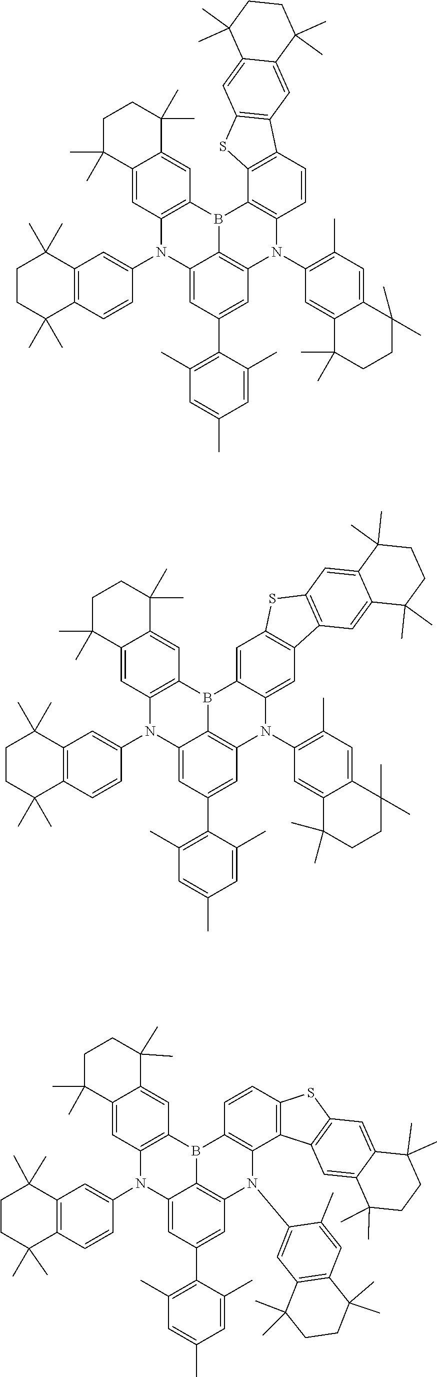 [SMILES: Cc1cc(C)c(-c2cc3c4c(c2)N(c2cc5c(cc2C)C(C)(C)CCC5(C)C)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

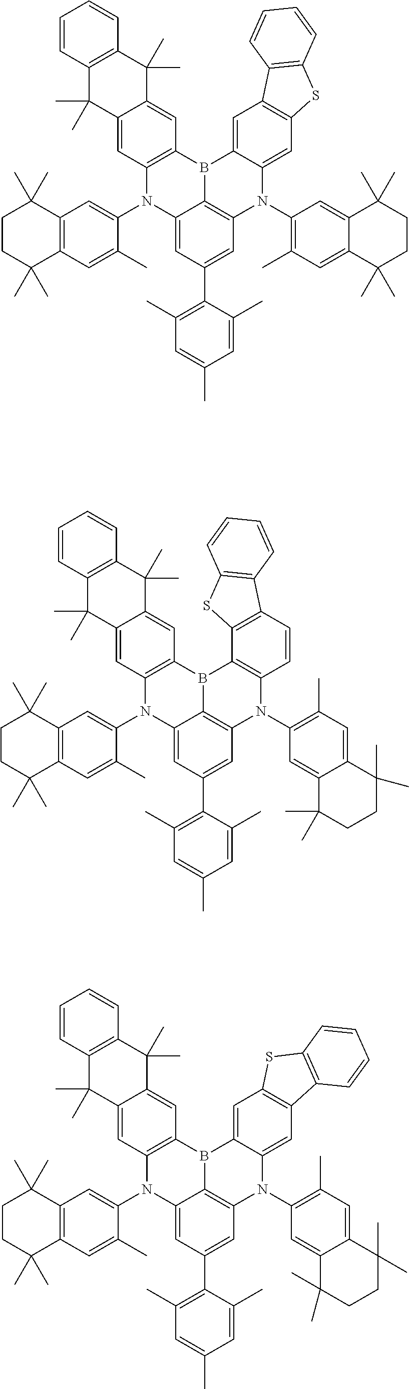 [SMILES: Cc1cc(C)c(-c2cc3c4c(c2)N(c2cc5c(cc2C)C(C)(C)CCC5(C)C)c2cc5sc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(sc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)sc2ccccc25)c(C)c1]

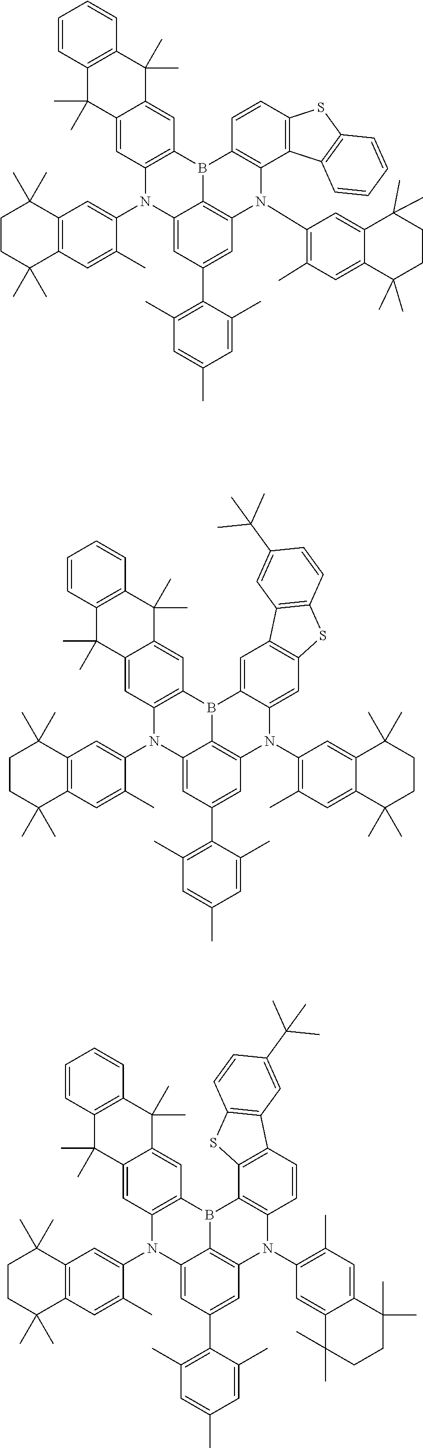 [SMILES: Cc1cc(C)c(-c2cc3c4c(c2)N(c2cc5c(cc2C)C(C)(C)CCC5(C)C)c2c(ccc5sc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5sc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(sc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1]

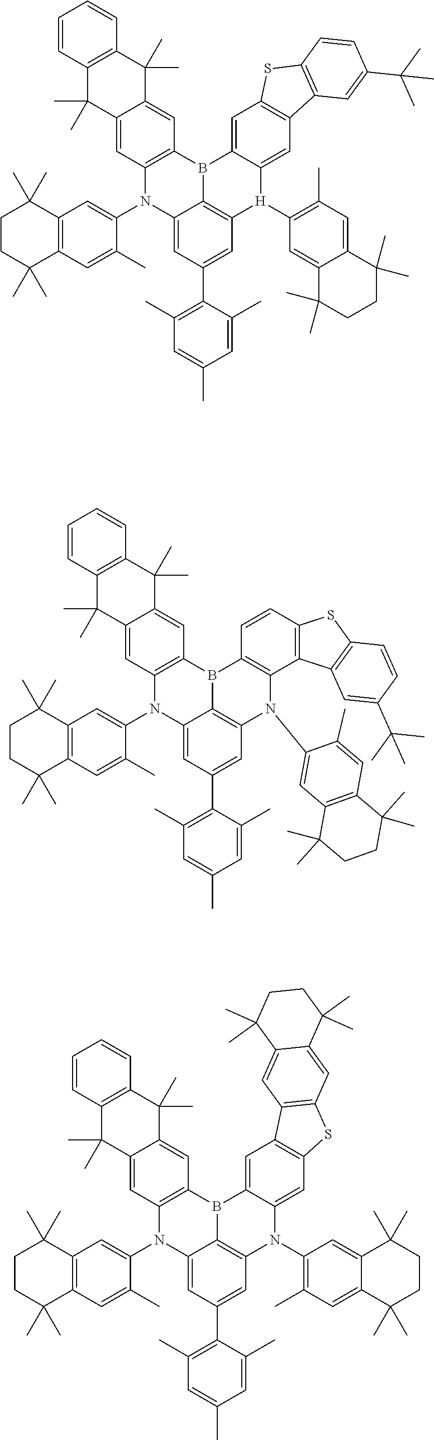

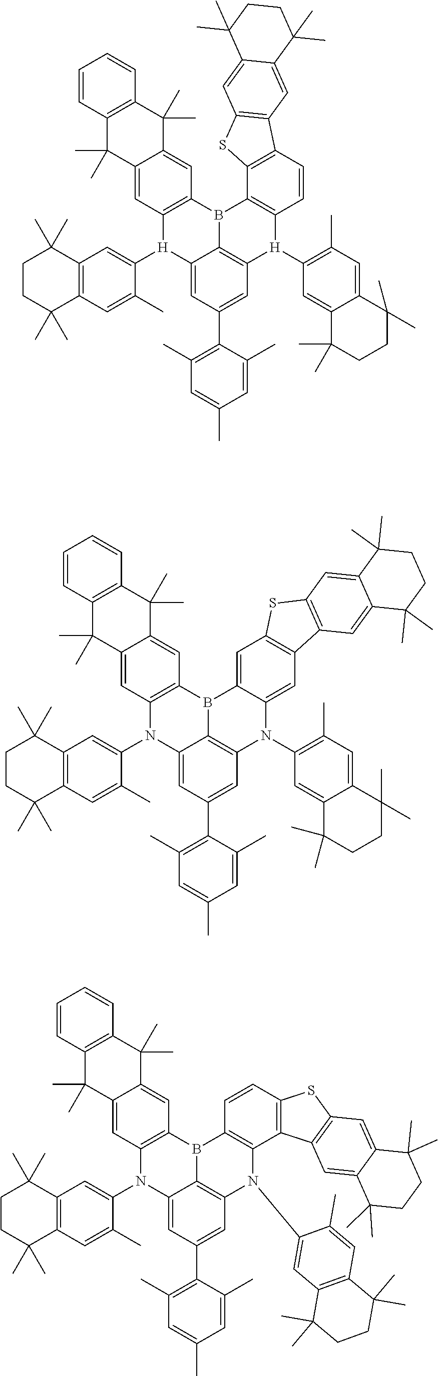

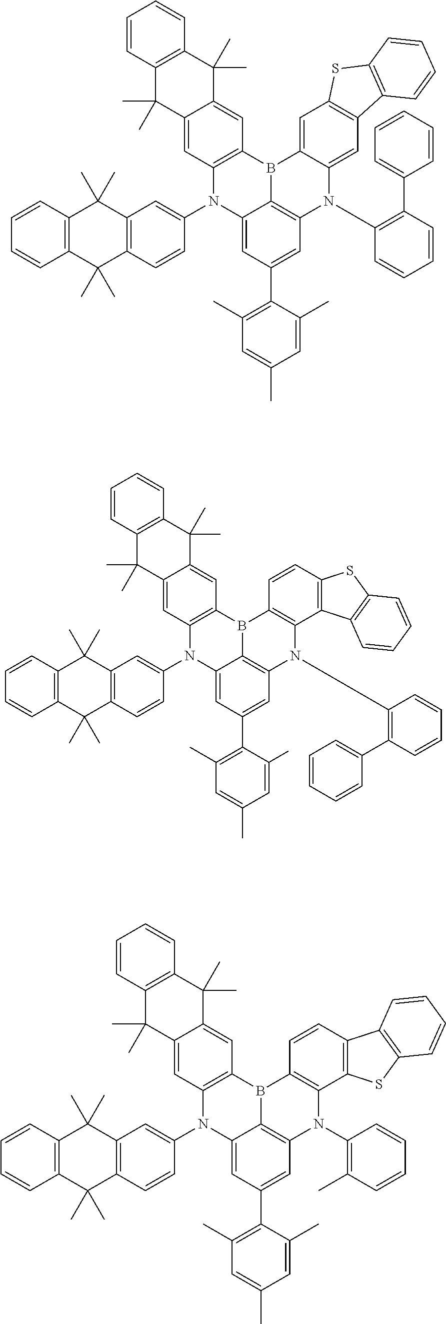 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1]

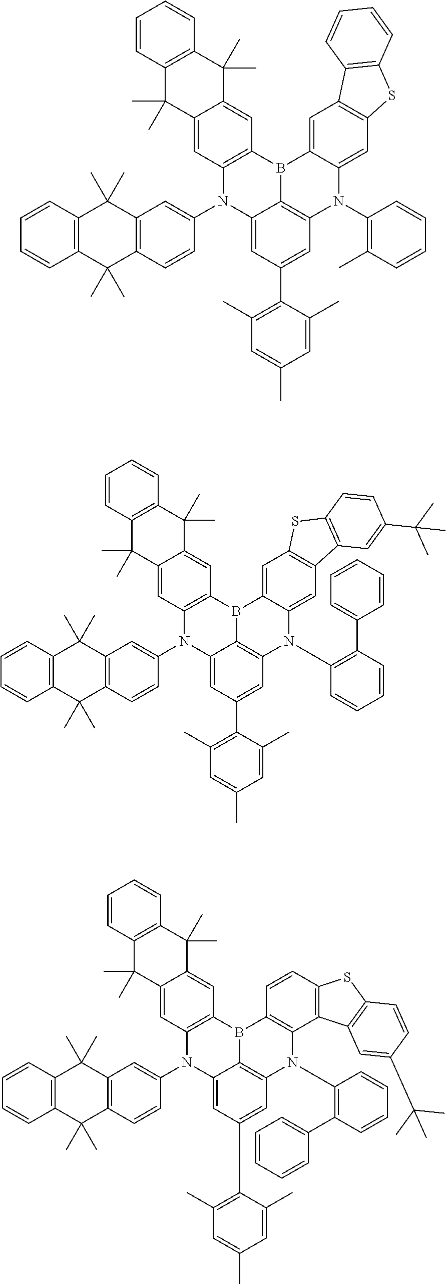 [SMILES: Cc1cc(C)c(-c2cc3c4c(c2)N(c2ccccc2C)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1 ; Cc1cc(C)c(-c2cc3c4c(c2)N(c2ccccc2-c2ccccc2)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1]

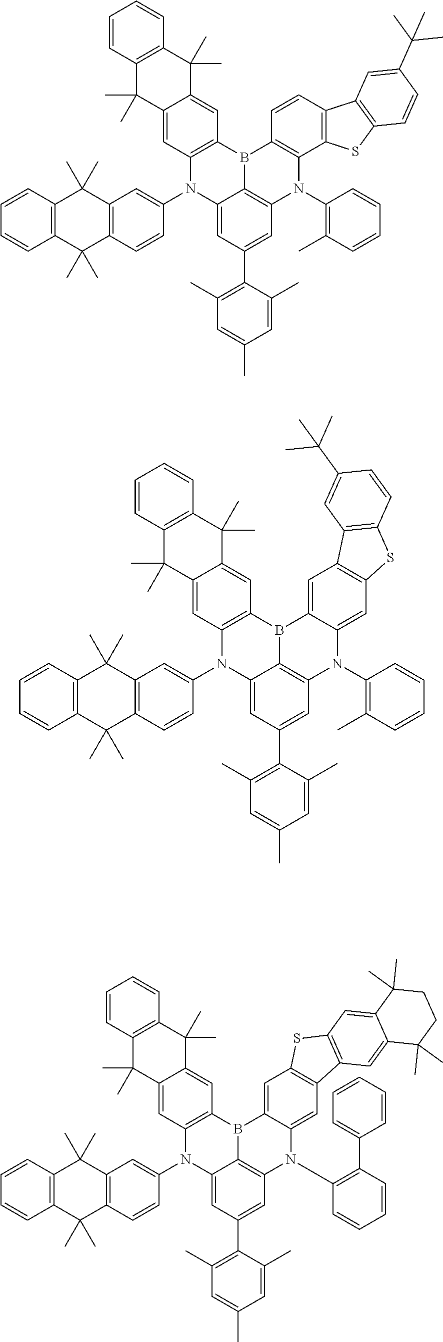 [SMILES: Cc1cc(C)c(-c2cc3c4c(c2)N(c2ccccc2C)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2cc3c(cc25)C(C)(C)CCC3(C)C)c(C)c1]

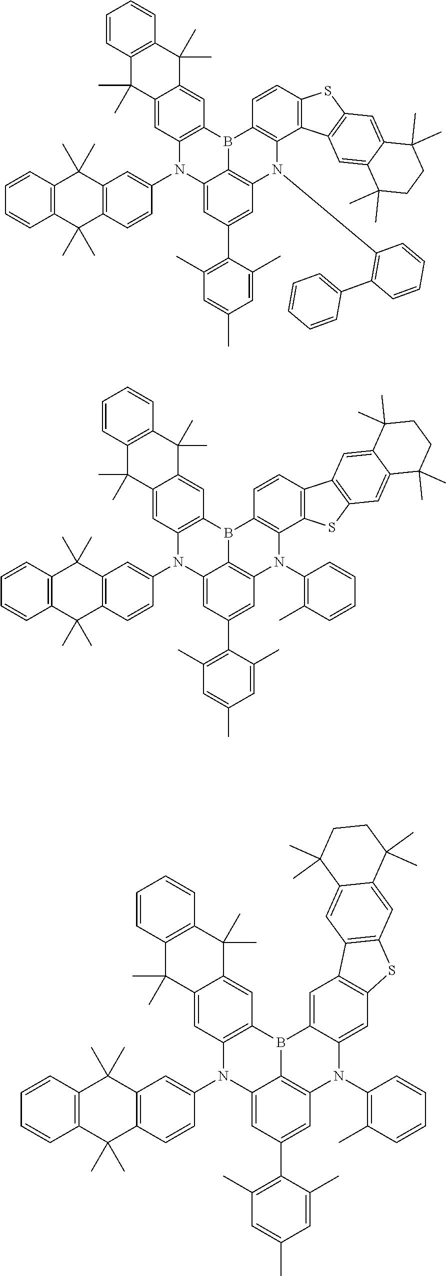 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5sc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

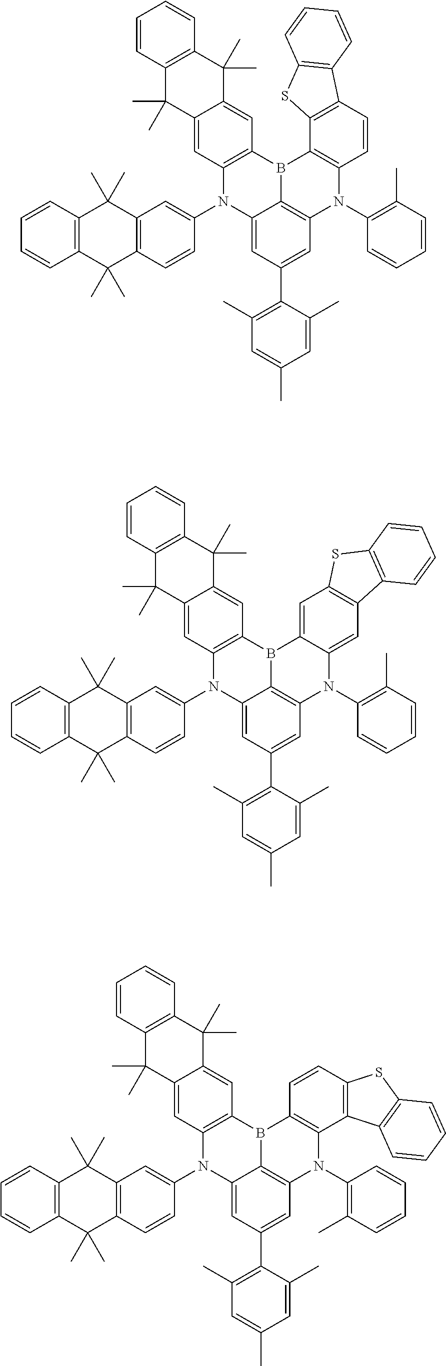 [SMILES: Cc1cc(C)c(-c2cc3c4c(c2)N(c2ccccc2C)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1]

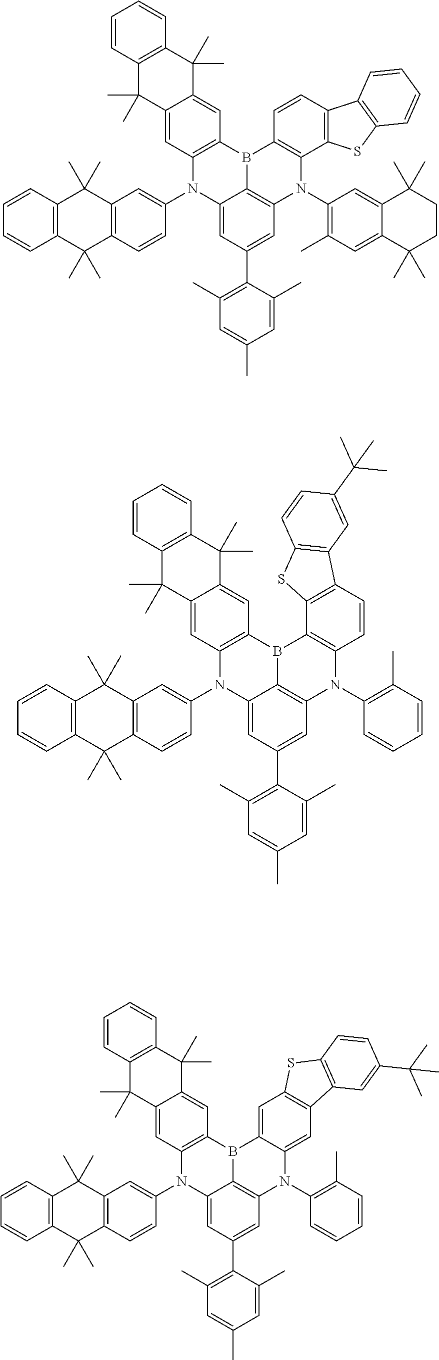 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1]

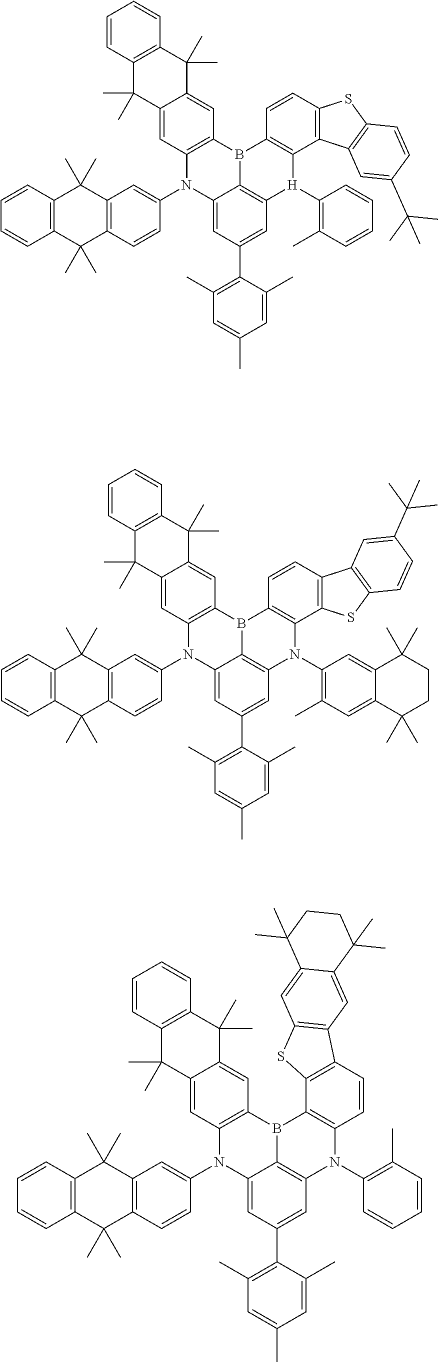

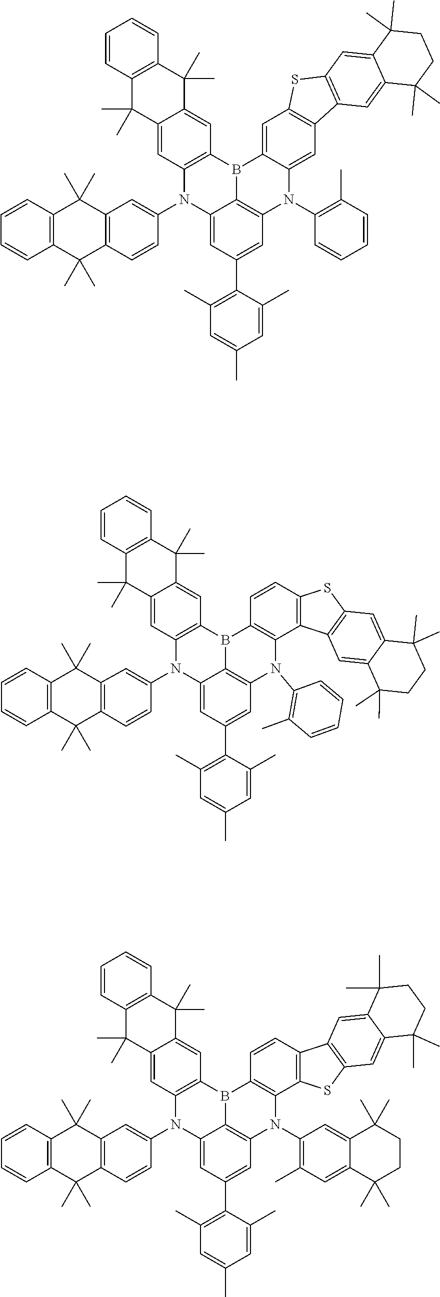 [SMILES: Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)sc2cc3c(cc25)C(C)(C)CCC3(C)C)c(C)c1 ; Cc1cc(C)c(-c2cc3c4c(c2)N(c2ccccc2C)c2c(ccc5sc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

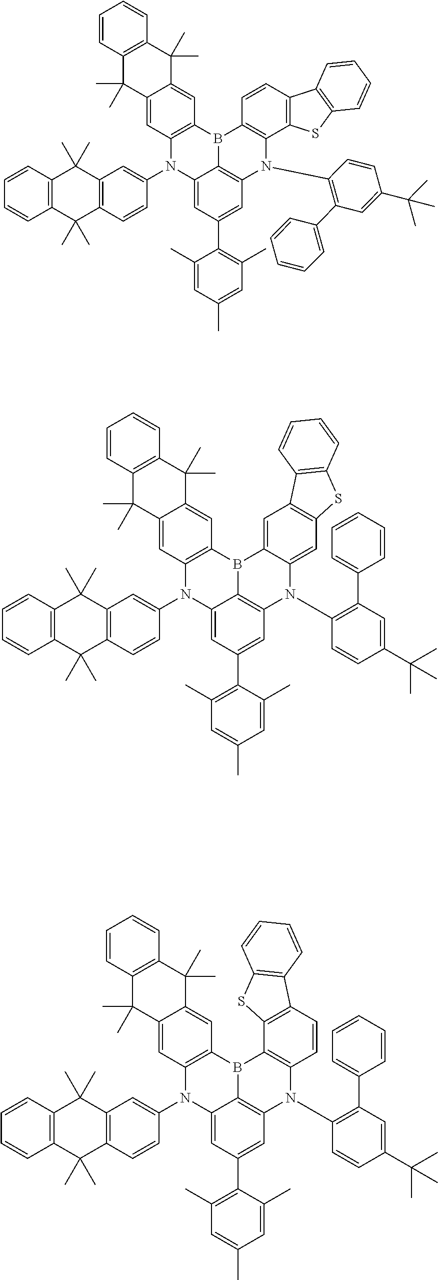 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1]

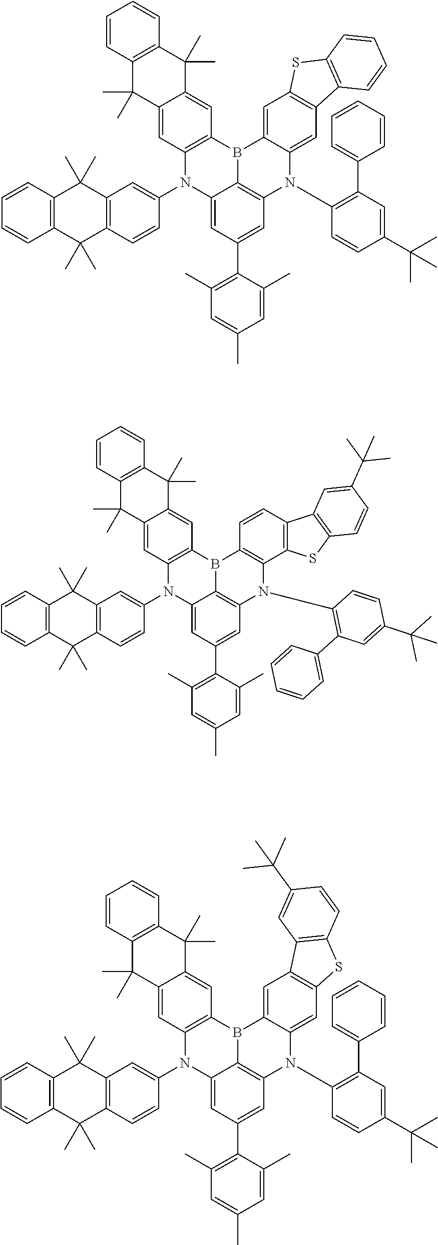 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1]

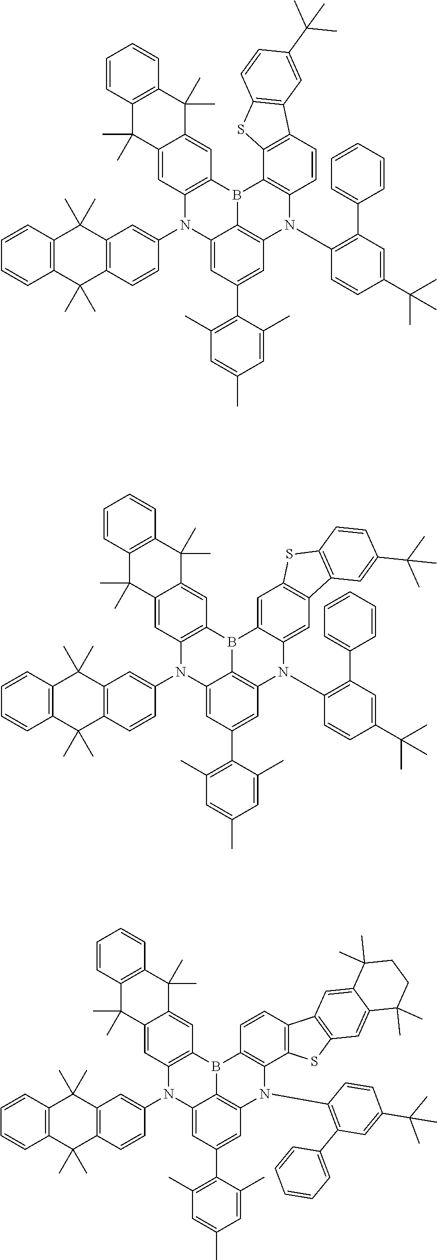 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

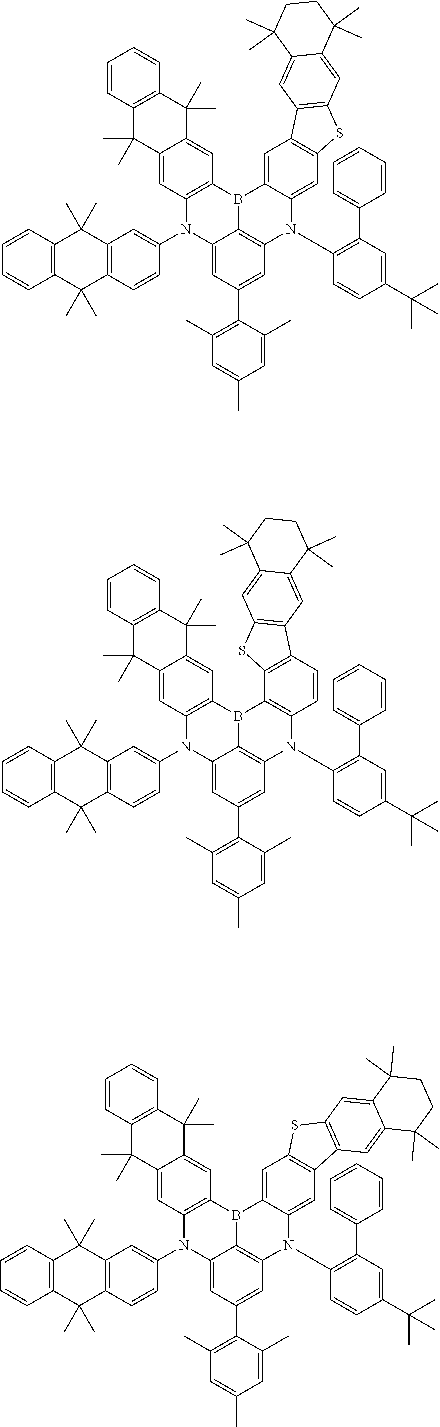

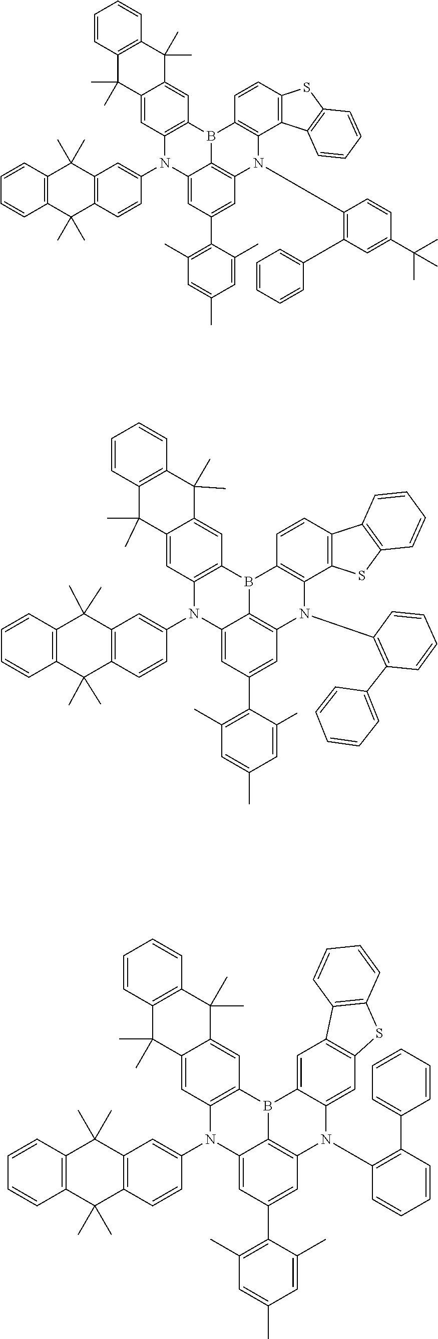 [SMILES: Cc1cc(C)c(-c2cc3c4c(c2)N(c2ccc(C(C)(C)C)cc2-c2ccccc2)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1]

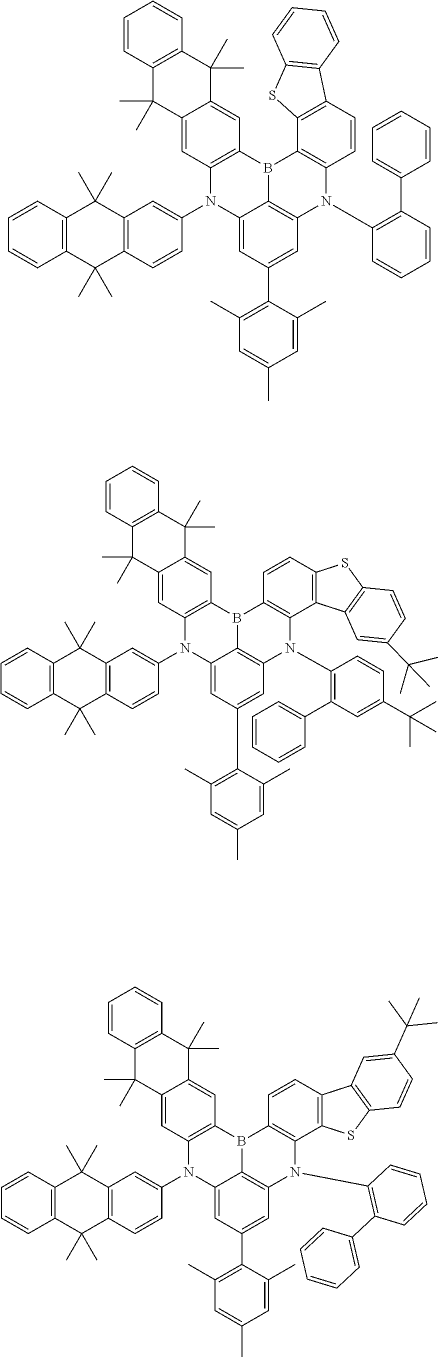 [SMILES: Cc1cc(C)c(-c2cc3c4c(c2)N(c2ccccc2-c2ccccc2)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1]

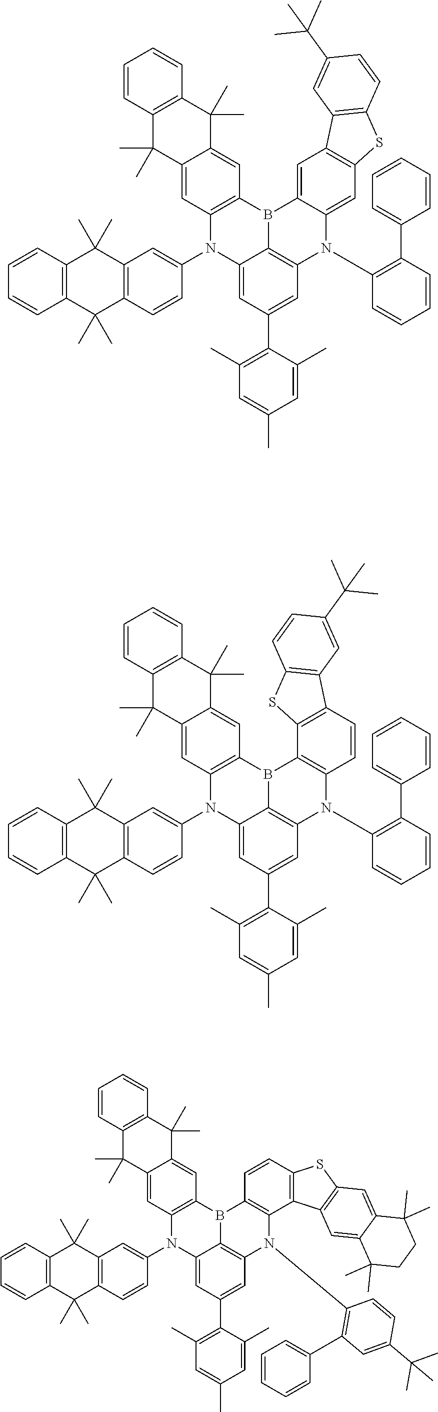 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1]

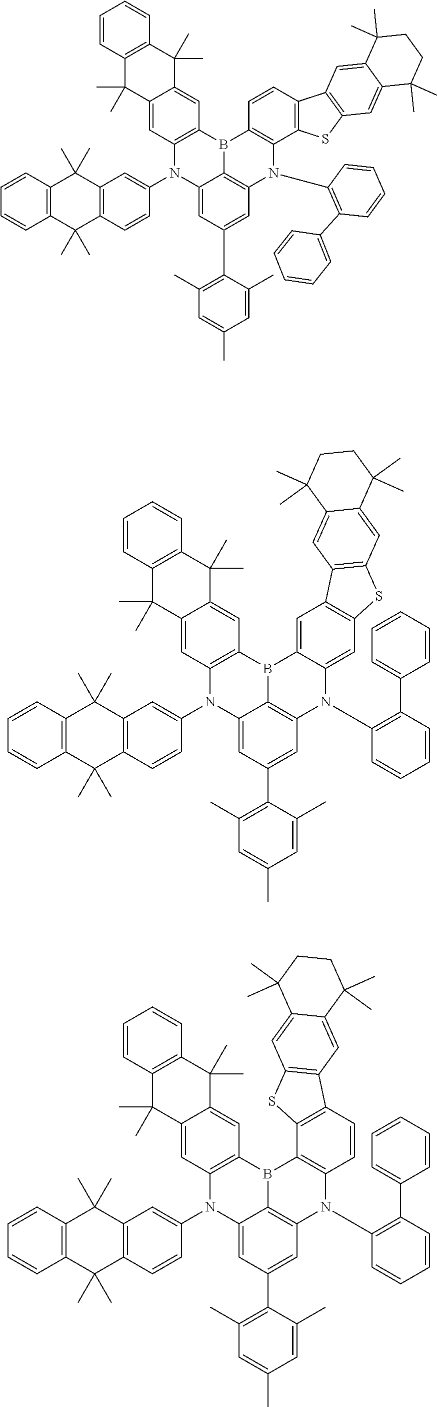 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

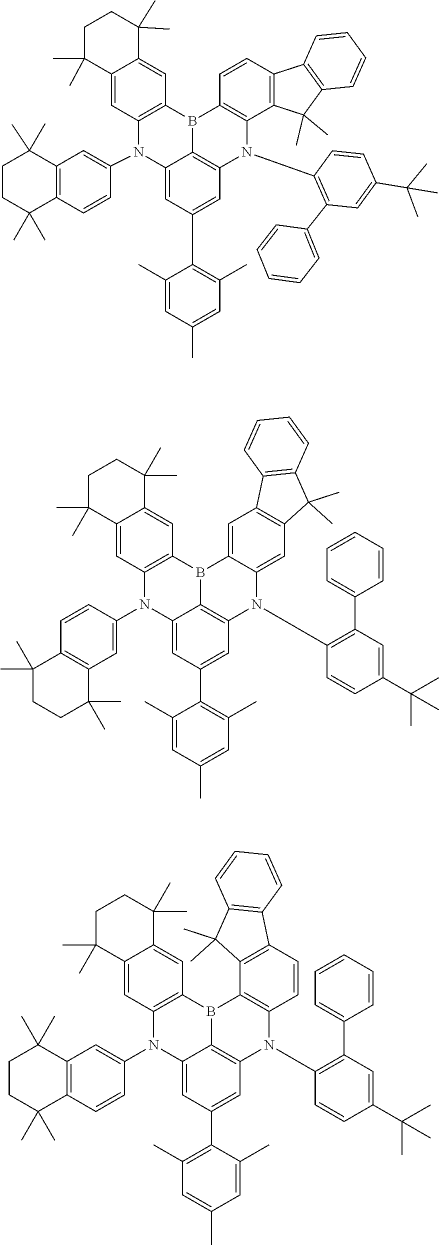

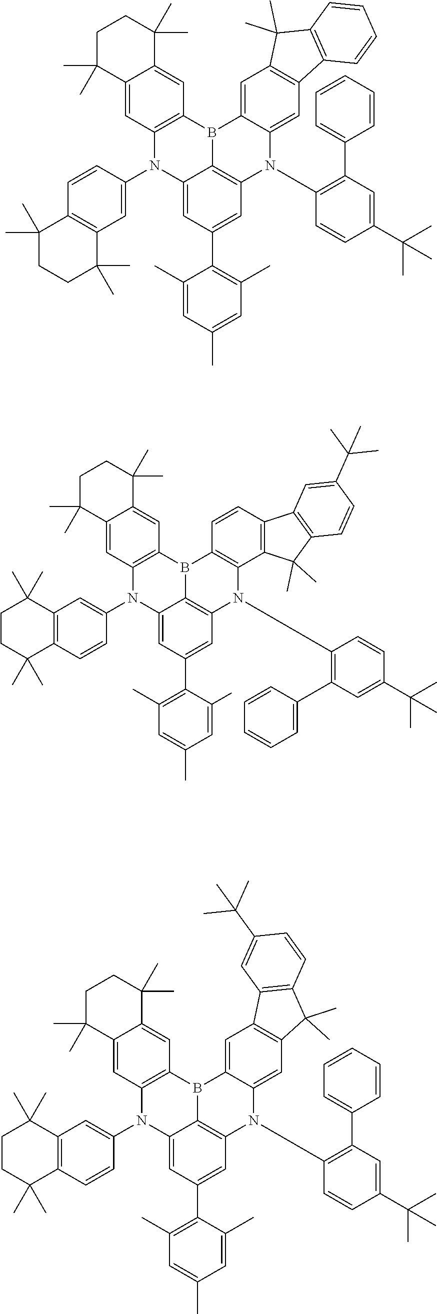 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccc(C(C)(C)C)cc2-c2ccccc2)c2c(ccc5c2C(C)(C)c2ccc(C(C)(C)C)cc2-5)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)-c2cc(C(C)(C)C)ccc2C5(C)C)c(C)c1]

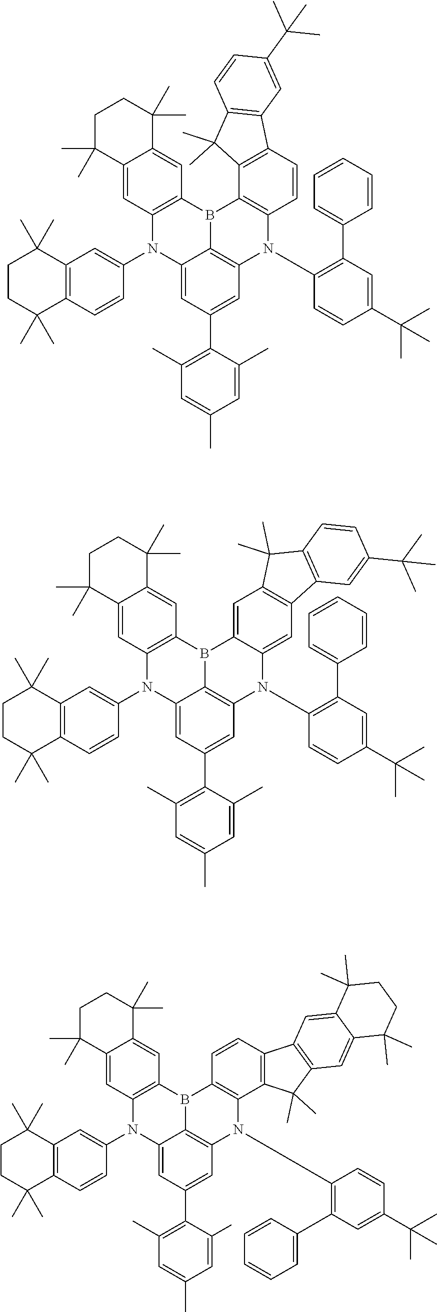 [SMILES: Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2C(C)(C)c2cc6c(cc2-5)C(C)(C)CCC6(C)C)B4c2cc4c(cc2N3c2ccc3c(c2)C(C)(C)CCC3(C)C)C(C)(C)CCC4(C)C)c(C)c1]

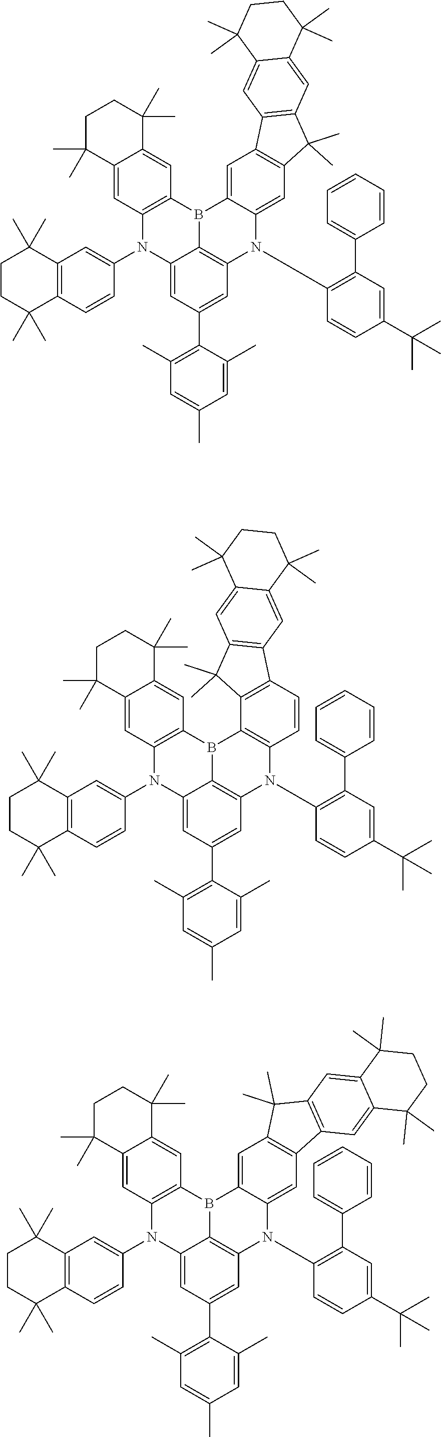 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)-c2cc3c(cc2C5(C)C)C(C)(C)CCC3(C)C)c(C)c1 ; Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1]

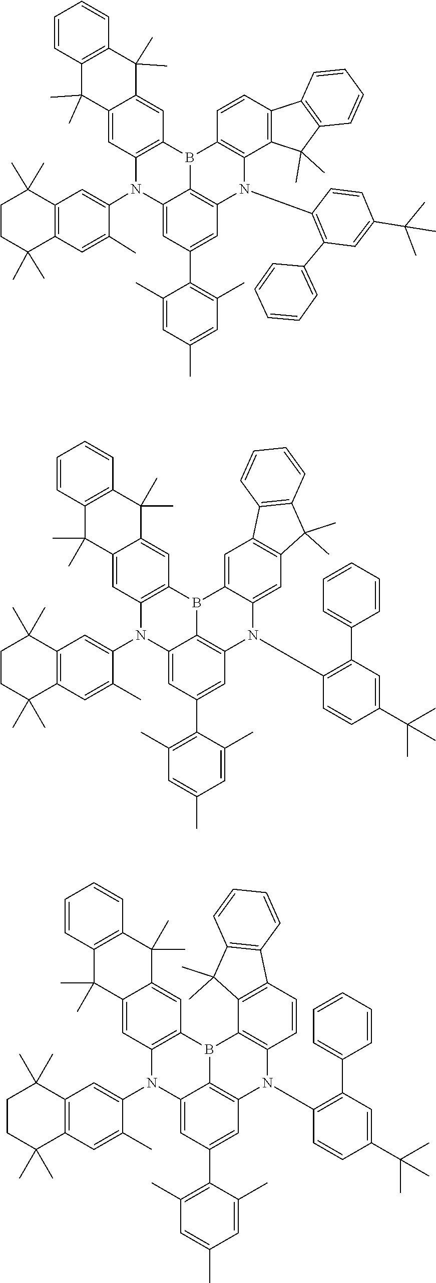 [SMILES: Cc1cc(C)c(-c2cc3c4c(c2)N(c2ccc(C(C)(C)C)cc2-c2ccccc2)c2c(ccc5c2C(C)(C)c2ccccc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)-c2ccccc2C5(C)C)c(C)c1 ; Cc1cc(C)c(-c2cc3c4c(c2)N(c2ccc(C(C)(C)C)cc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2ccccc2-5)c(C)c1]

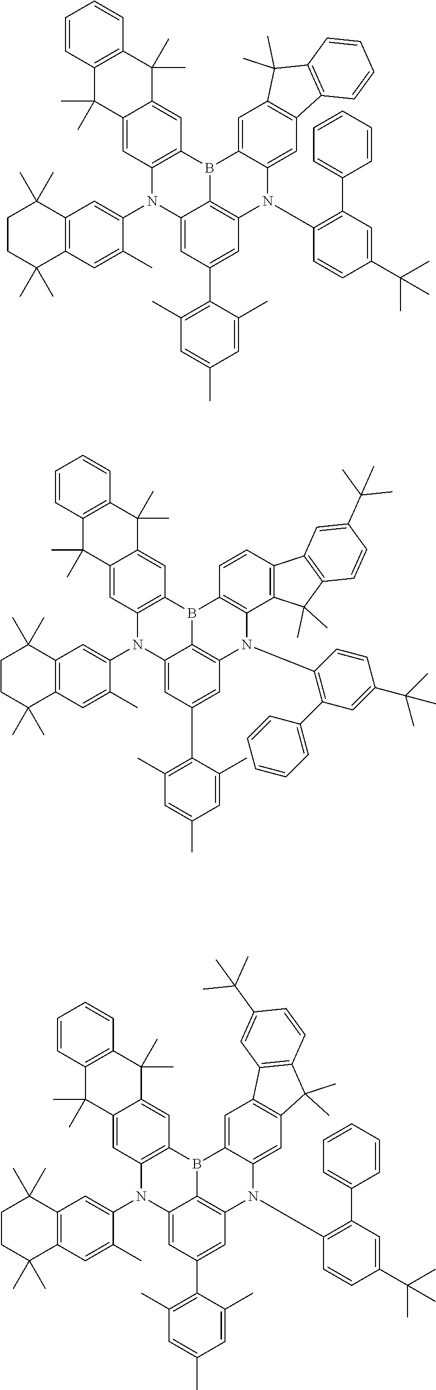 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2ccccc2-5)c(C)c1 ; Cc1cc(C)c(-c2cc3c4c(c2)N(c2ccc(C(C)(C)C)cc2-c2ccccc2)c2c(ccc5c2C(C)(C)c2ccc(C(C)(C)C)cc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)-c2cc(C(C)(C)C)ccc2C5(C)C)c(C)c1]

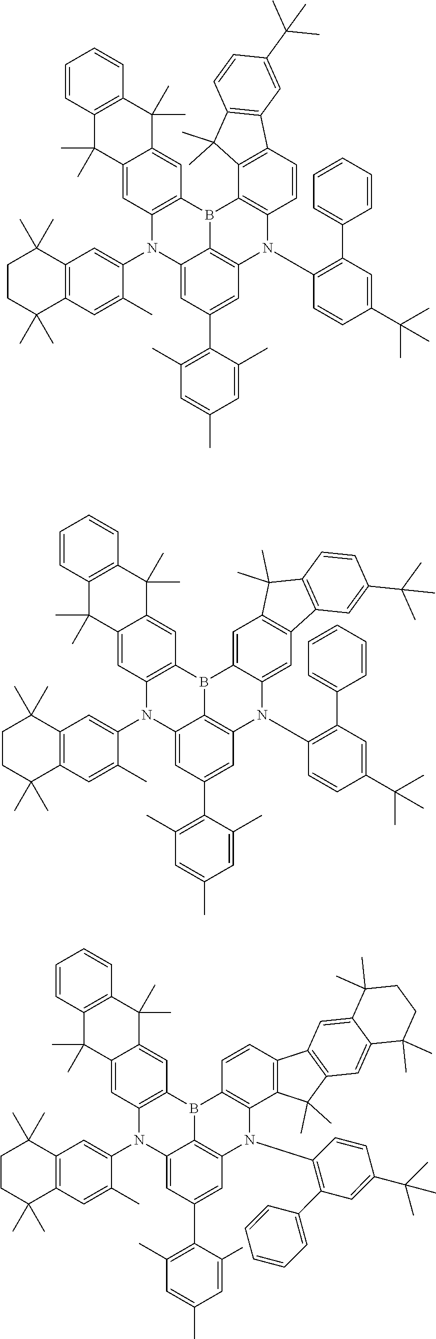 [SMILES: Cc1cc(C)c(-c2cc3c4c(c2)N(c2ccc(C(C)(C)C)cc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2C(C)(C)c2cc6c(cc2-5)C(C)(C)CCC6(C)C)B4c2cc4c(cc2N3c2cc3c(cc2C)C(C)(C)CCC3(C)C)C(C)(C)c2ccccc2C4(C)C)c(C)c1]

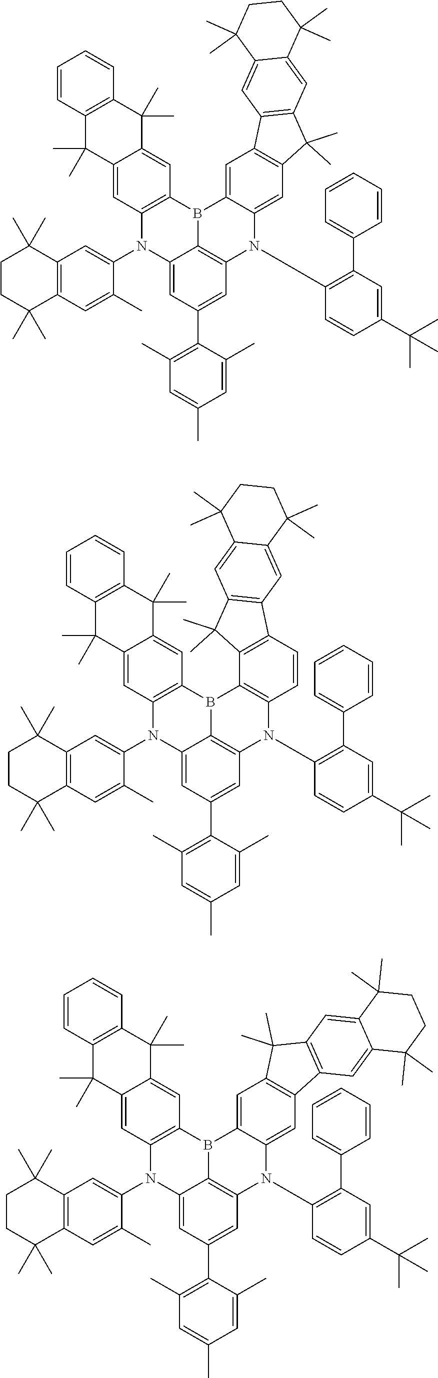

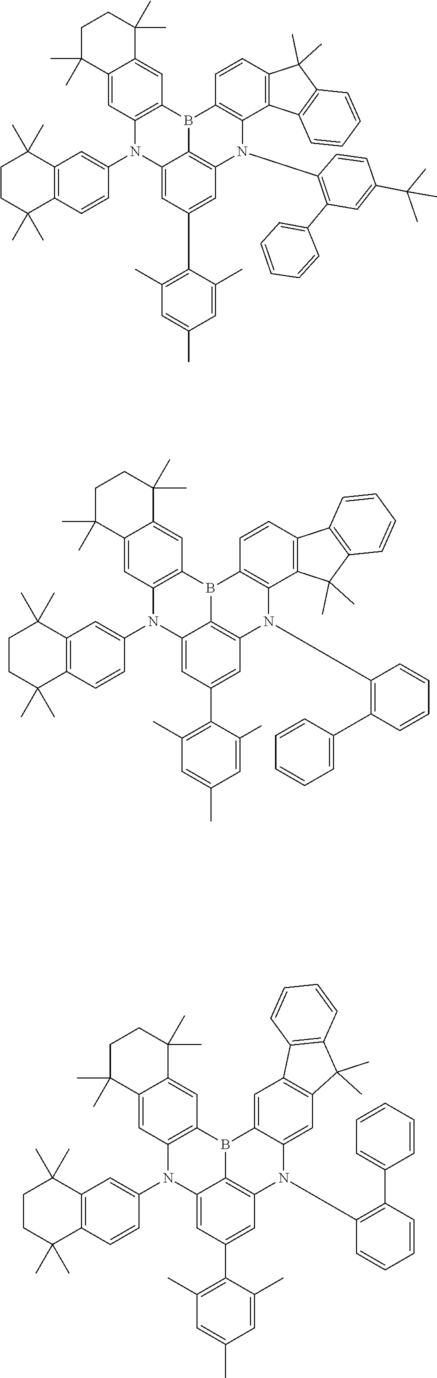 [SMILES: Cc1cc(C)c(-c2cc3c4c(c2)N(c2ccc(C(C)(C)C)cc2-c2ccccc2)c2c(ccc5c2-c2ccccc2C5(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2C(C)(C)c2ccccc2-5)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)-c2ccccc2C5(C)C)c(C)c1]

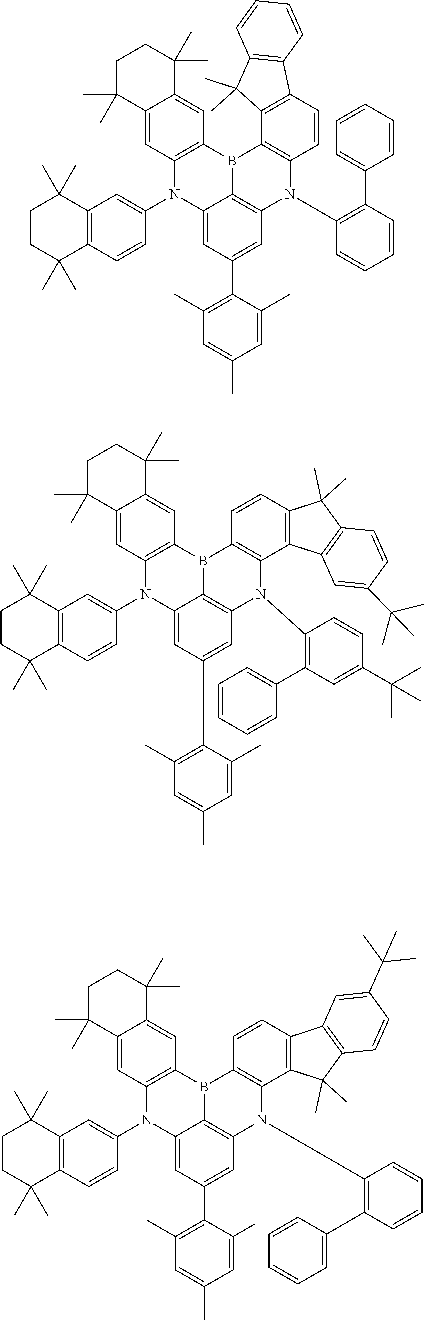 [SMILES: Cc1cc(C)c(-c2cc3c4c(c2)N(c2ccccc2-c2ccccc2)c2ccc5c(c2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccc(C(C)(C)C)cc2-c2ccccc2)c2c(ccc5c2-c2cc(C(C)(C)C)ccc2C5(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2C(C)(C)c2ccc(C(C)(C)C)cc2-5)B4c2cc4c(cc2N3c2ccc3c(c2)C(C)(C)CCC3(C)C)C(C)(C)CCC4(C)C)c(C)c1]

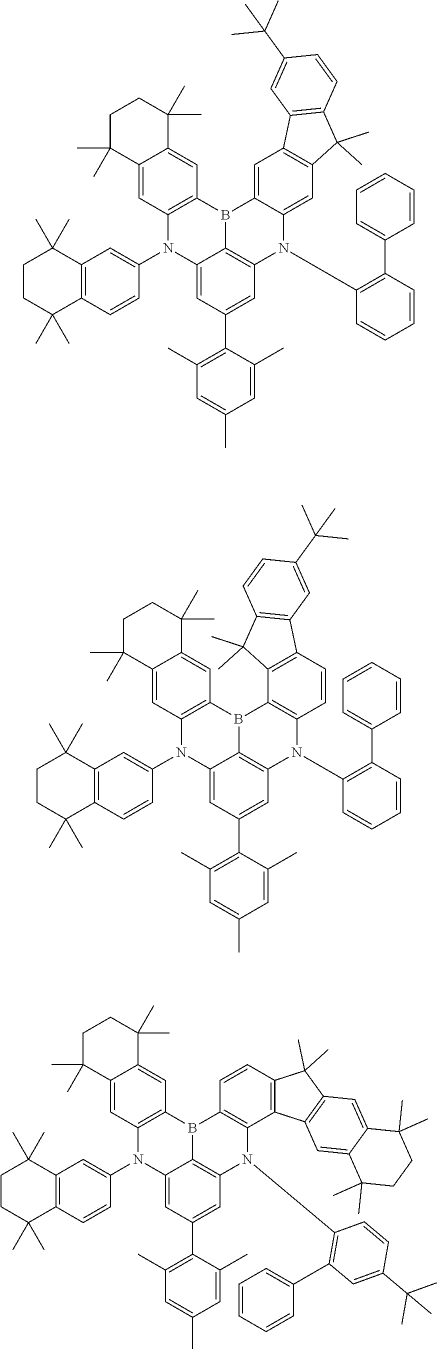 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)-c2cc(C(C)(C)C)ccc2C5(C)C)c(C)c1 ; Cc1cc(C)c(-c2cc3c4c(c2)N(c2ccccc2-c2ccccc2)c2ccc5c(c2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2-c2cc6c(cc2C5(C)C)C(C)(C)CCC6(C)C)B4c2cc4c(cc2N3c2ccc3c(c2)C(C)(C)CCC3(C)C)C(C)(C)CCC4(C)C)c(C)c1]

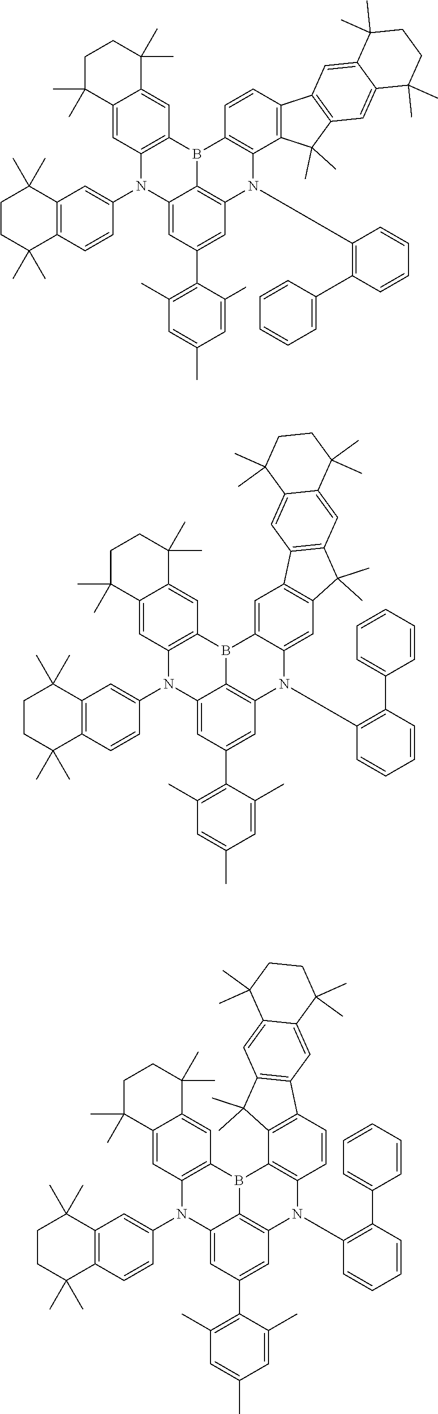 [SMILES: Cc1cc(C)c(-c2cc3c4c(c2)N(c2ccccc2-c2ccccc2)c2c(ccc5c2C(C)(C)c2cc6c(cc2-5)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)-c2cc3c(cc2C5(C)C)C(C)(C)CCC3(C)C)c(C)c1 ; Cc1cc(C)c(-c2cc3c4c(c2)N(c2ccccc2-c2ccccc2)c2ccc5c(c2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1]

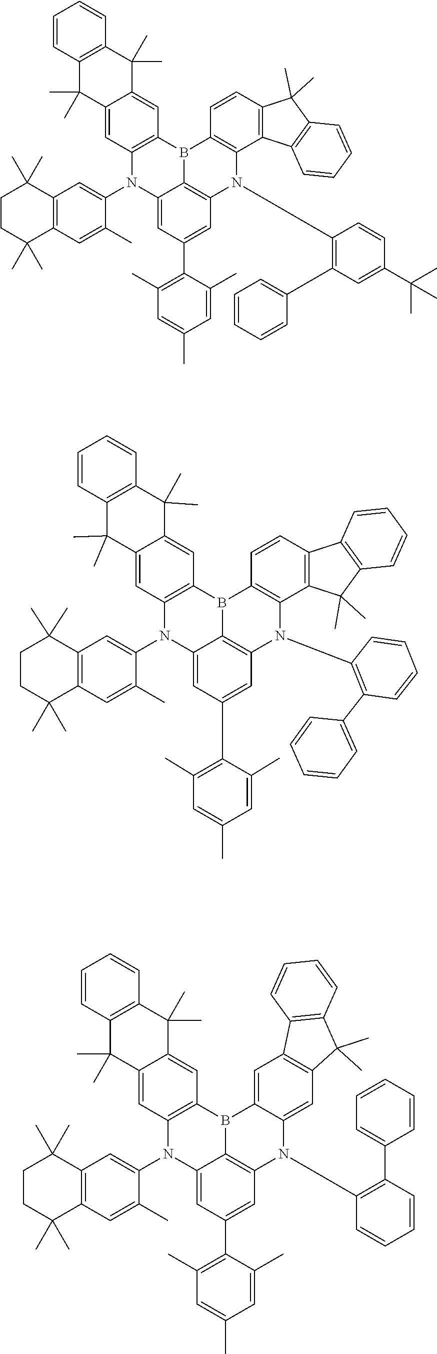 [SMILES: Cc1cc(C)c(-c2cc3c4c(c2)N(c2ccc(C(C)(C)C)cc2-c2ccccc2)c2c(ccc5c2-c2ccccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2C(C)(C)c2ccccc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)-c2ccccc2C5(C)C)c(C)c1]

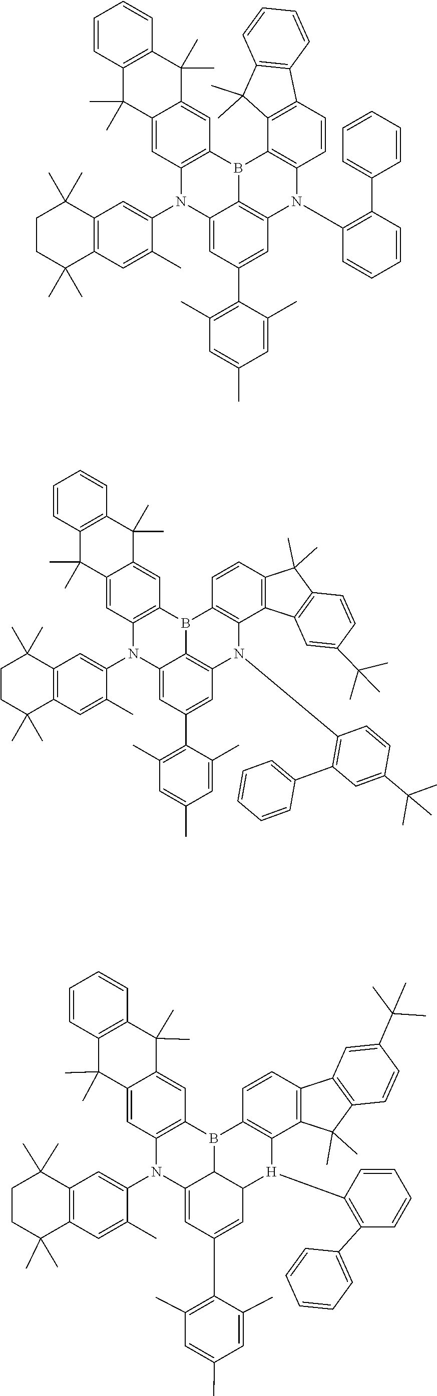

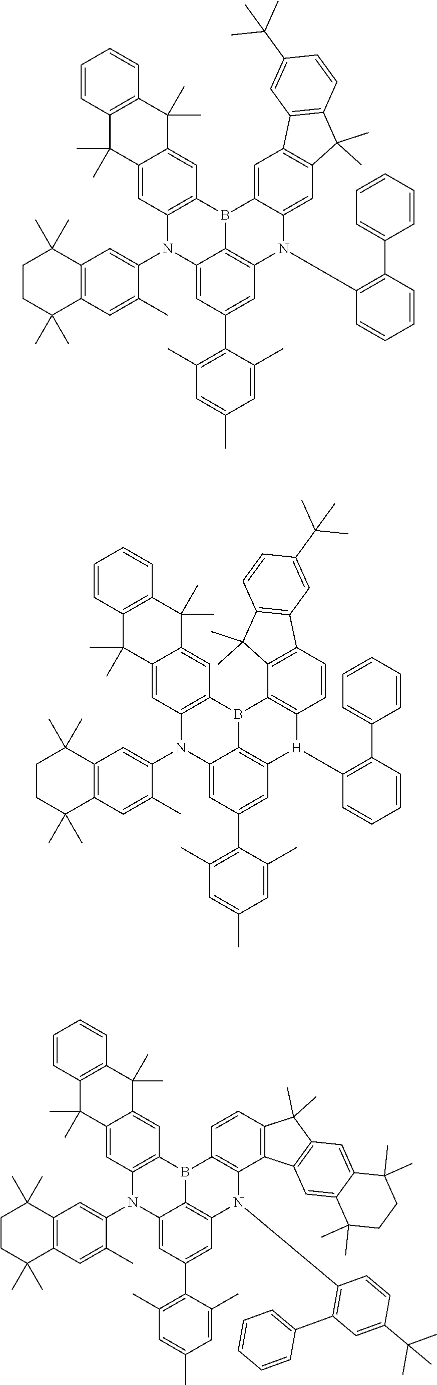

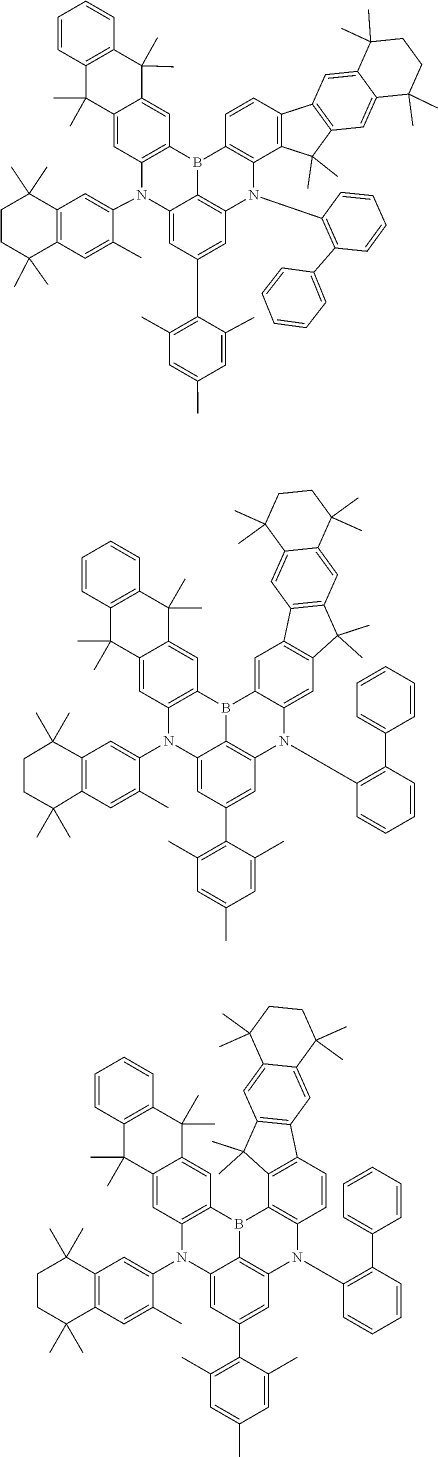 [SMILES: Cc1cc(C)c(-c2cc3c4c(c2)N(c2ccccc2-c2ccccc2)c2c(ccc5c2C(C)(C)c2cc6c(cc2-5)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)-c2cc3c(cc2C5(C)C)C(C)(C)CCC3(C)C)c(C)c1 ; Cc1cc(C)c(-c2cc3c4c(c2)N(c2ccccc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2cc3c(cc2-5)C(C)(C)CCC3(C)C)c(C)c1]

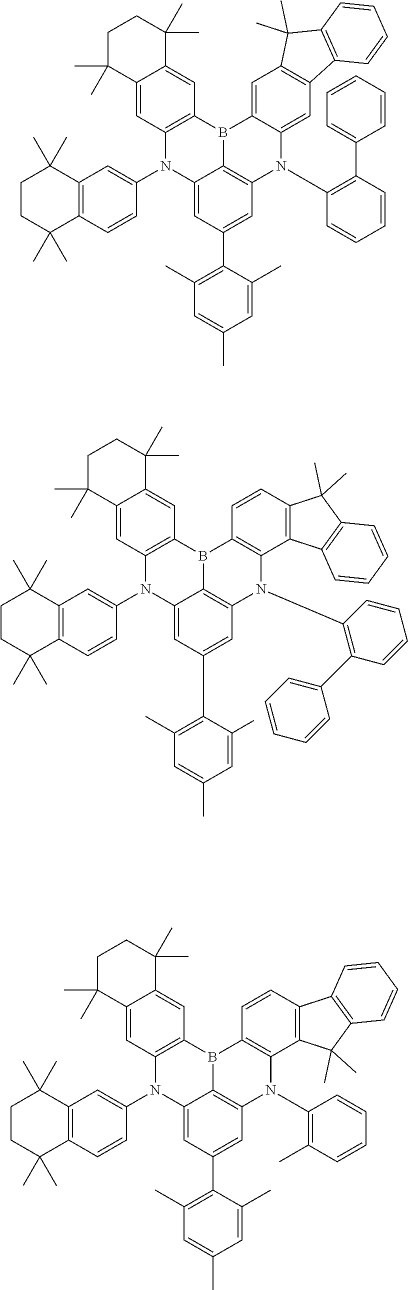 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccccc2-c2ccccc2)c2c(ccc5c2-c2ccccc2C5(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2C(C)(C)c2ccccc2-5)B4c2cc4c(cc2N3c2ccc3c(c2)C(C)(C)CCC3(C)C)C(C)(C)CCC4(C)C)c(C)c1]

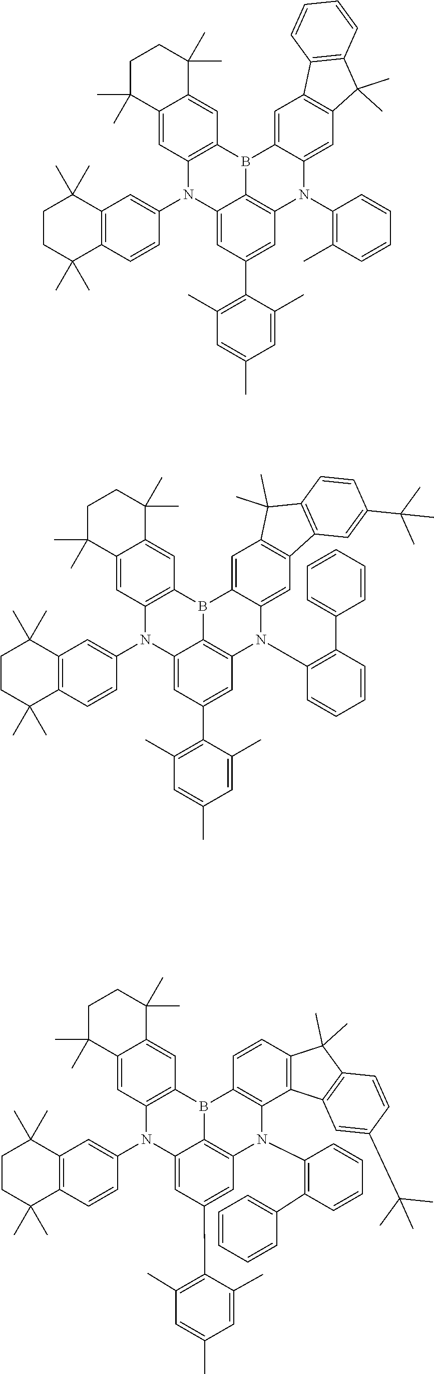 [SMILES: Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)-c2ccccc2C5(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccccc2-c2ccccc2)c2c(ccc5c2-c2cc(C(C)(C)C)ccc2C5(C)C)B4c2cc4c(cc2N3c2ccc3c(c2)C(C)(C)CCC3(C)C)C(C)(C)CCC4(C)C)c(C)c1]

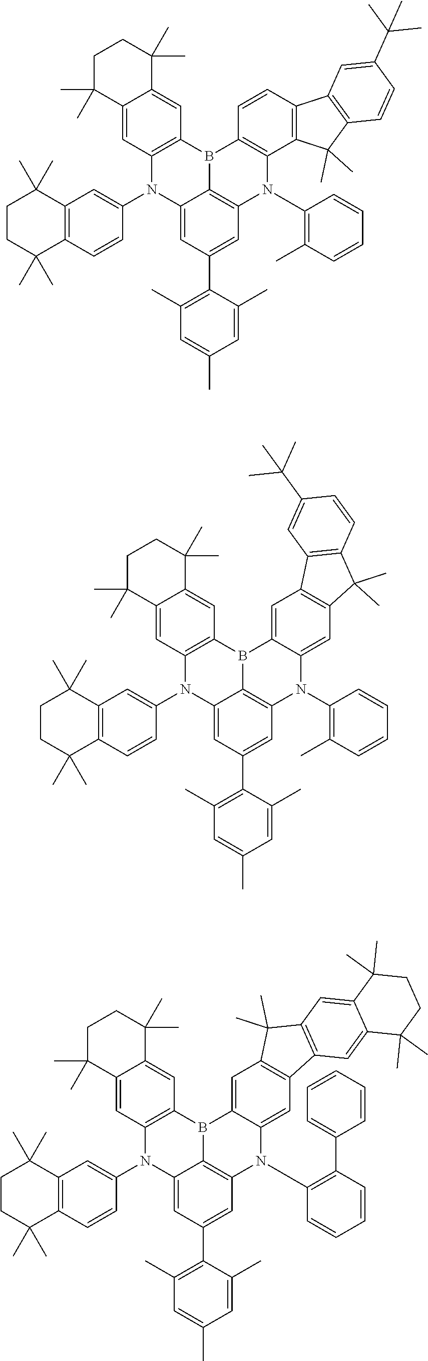 [SMILES: Cc1cc(C)c(-c2cc3c4c(c2)N(c2ccccc2C)c2c(ccc5c2C(C)(C)c2ccc(C(C)(C)C)cc2-5)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)-c2cc(C(C)(C)C)ccc2C5(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1]

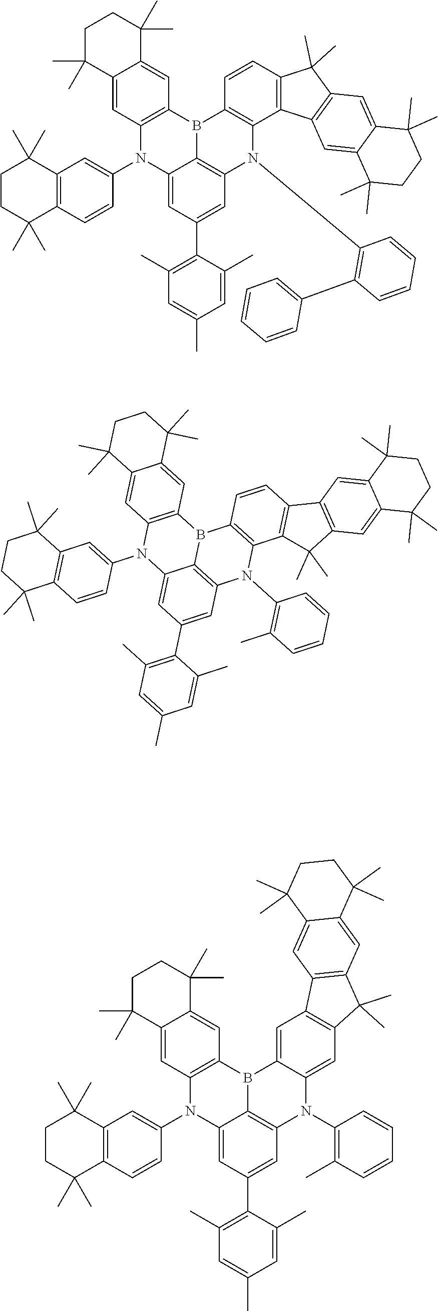 [SMILES: Cc1cc(C)c(-c2cc3c4c(c2)N(c2ccccc2-c2ccccc2)c2c(ccc5c2-c2cc6c(cc2C5(C)C)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2C(C)(C)c2cc6c(cc2-5)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)-c2cc3c(cc2C5(C)C)C(C)(C)CCC3(C)C)c(C)c1]

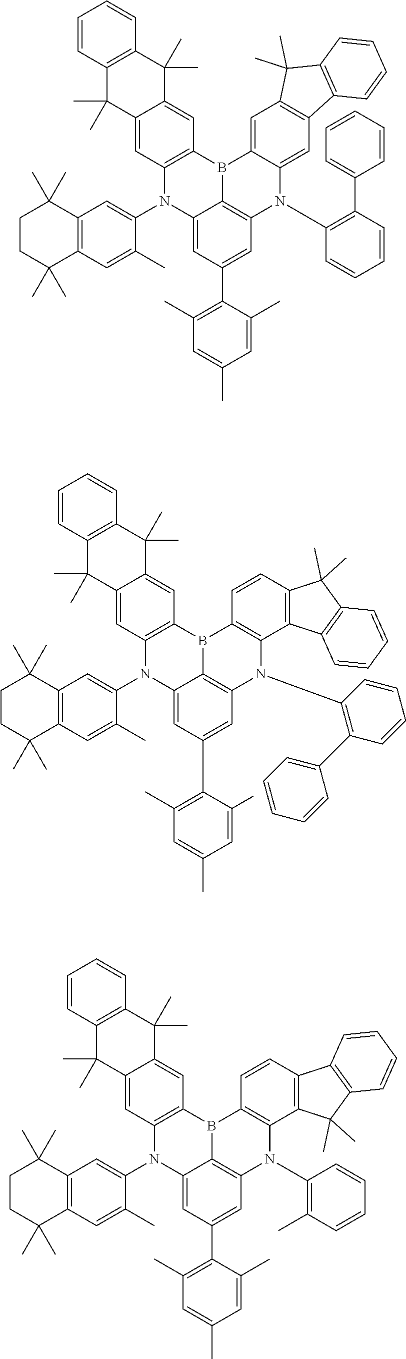 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2ccccc2-5)c(C)c1 ; Cc1cc(C)c(-c2cc3c4c(c2)N(c2ccccc2-c2ccccc2)c2c(ccc5c2-c2ccccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2C(C)(C)c2ccccc2-5)B4c2cc4c(cc2N3c2cc3c(cc2C)C(C)(C)CCC3(C)C)C(C)(C)c2ccccc2C4(C)C)c(C)c1]

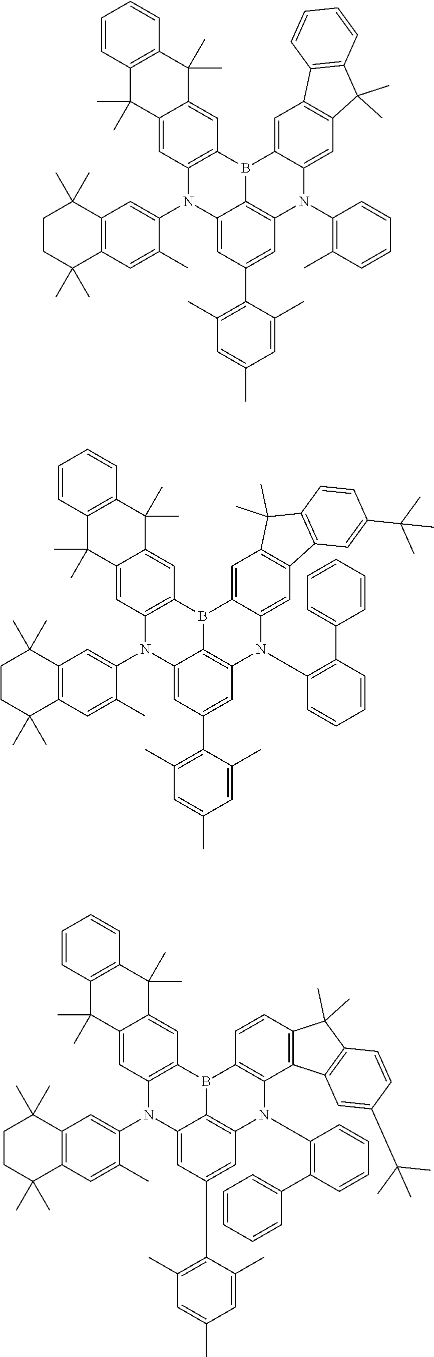 [SMILES: Cc1cc(C)c(-c2cc3c4c(c2)N(c2cc5c(cc2C)C(C)(C)CCC5(C)C)c2cc5c(cc2B4c2cc4c(cc2N3c2ccccc2C)C(C)(C)c2ccccc2-4)C(C)(C)c2ccccc2C5(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccccc2-c2ccccc2)c2c(ccc5c2-c2cc(C(C)(C)C)ccc2C5(C)C)B4c2cc4c(cc2N3c2cc3c(cc2C)C(C)(C)CCC3(C)C)C(C)(C)c2ccccc2C4(C)C)c(C)c1]

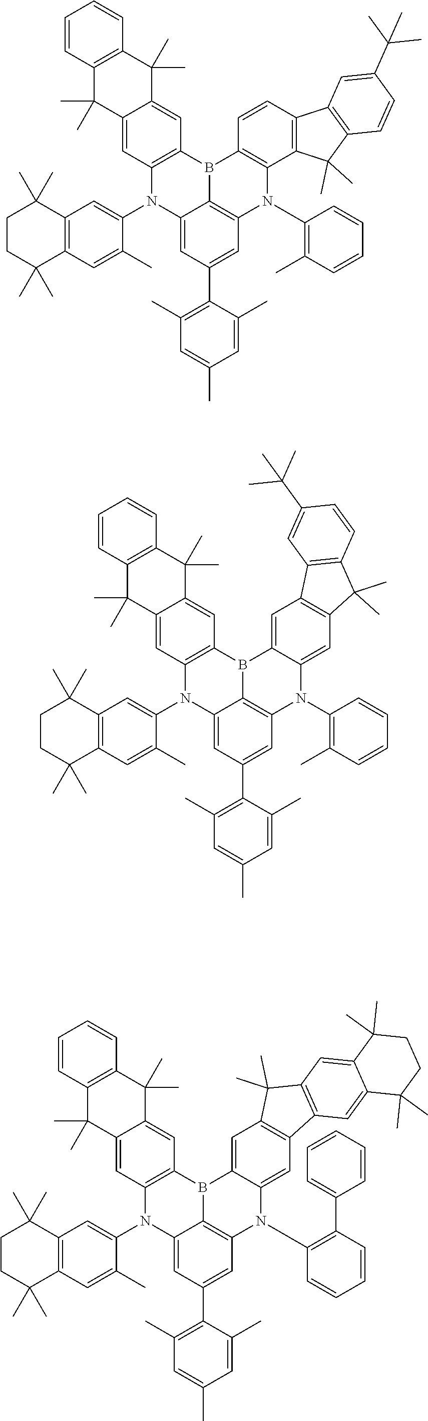 [SMILES: Cc1cc(C)c(-c2cc3c4c(c2)N(c2ccccc2C)c2c(ccc5c2C(C)(C)c2ccc(C(C)(C)C)cc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccccc2C)C(C)(C)c2ccc(C(C)(C)C)cc2-4)C(C)(C)c2ccccc2C5(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2cc3c(cc2-5)C(C)(C)CCC3(C)C)c(C)c1]

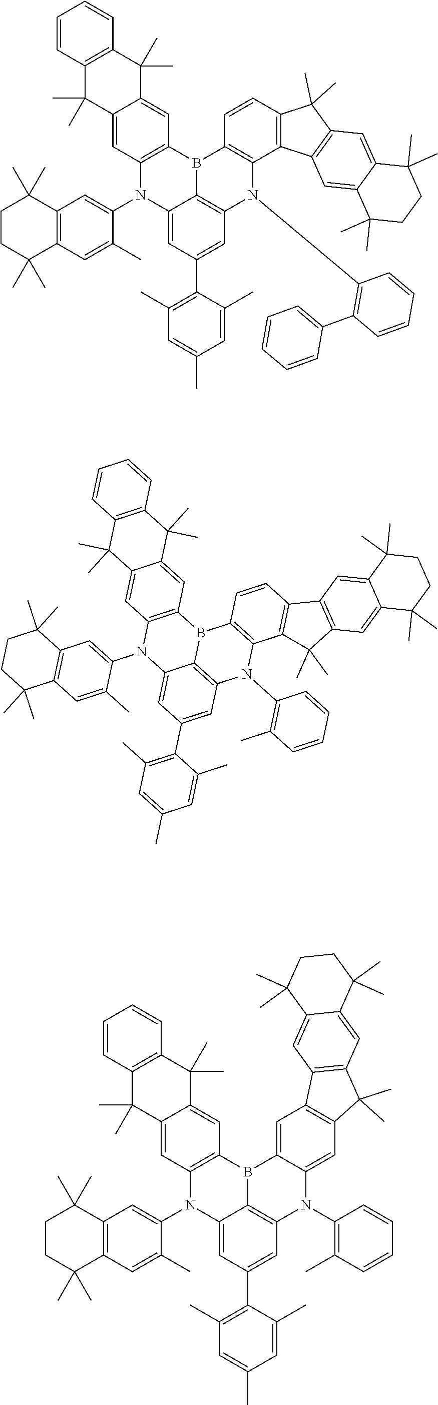 [SMILES: Cc1cc(C)c(-c2cc3c4c(c2)N(c2ccccc2-c2ccccc2)c2c(ccc5c2-c2cc6c(cc2C5(C)C)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2C(C)(C)c2cc6c(cc2-5)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccccc2C)C(C)(C)c2cc3c(cc2-4)C(C)(C)CCC3(C)C)C(C)(C)c2ccccc2C5(C)C)c(C)c1]

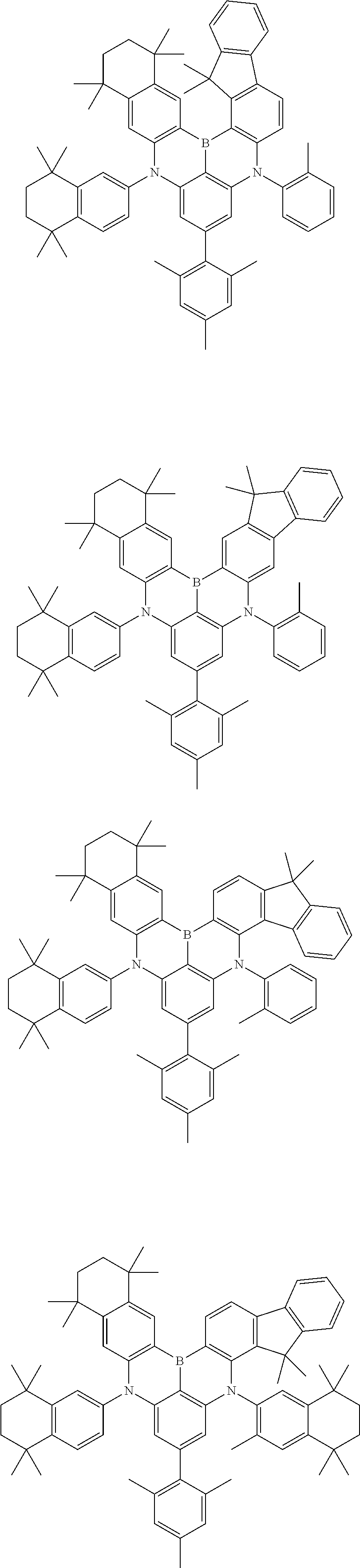

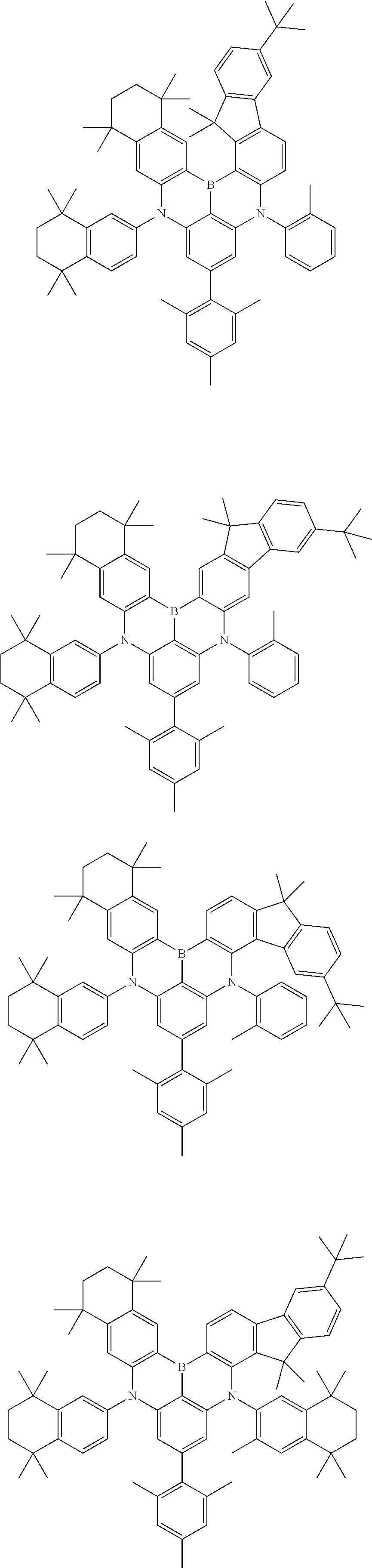

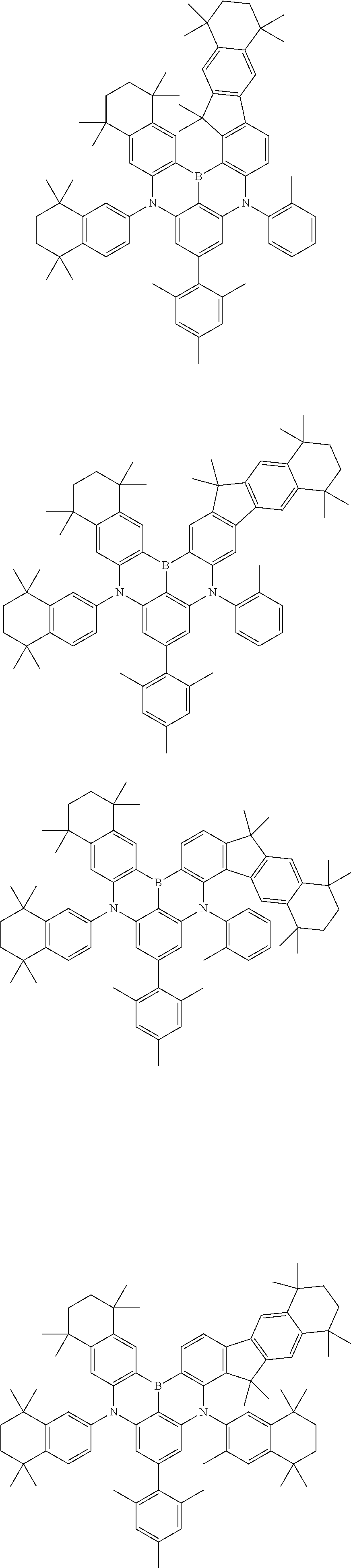

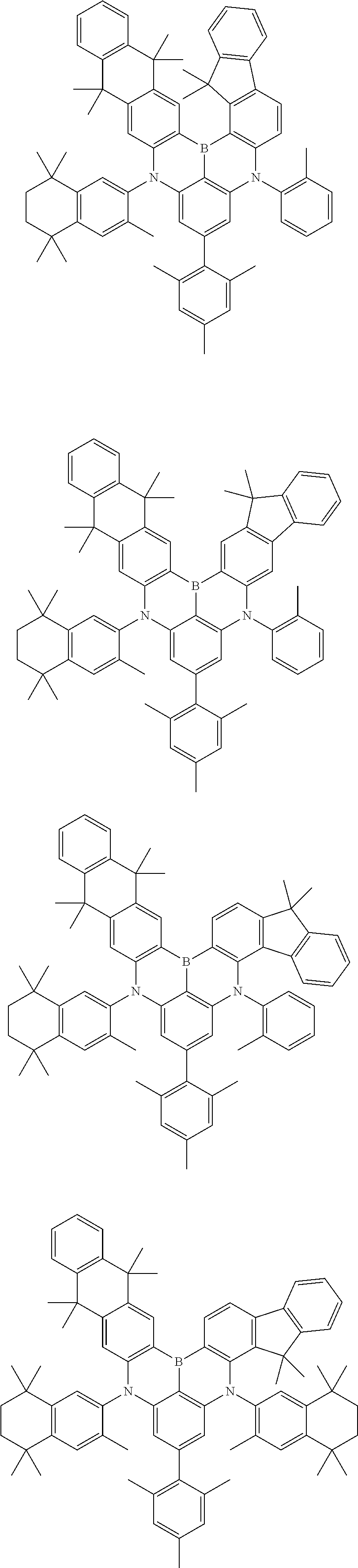

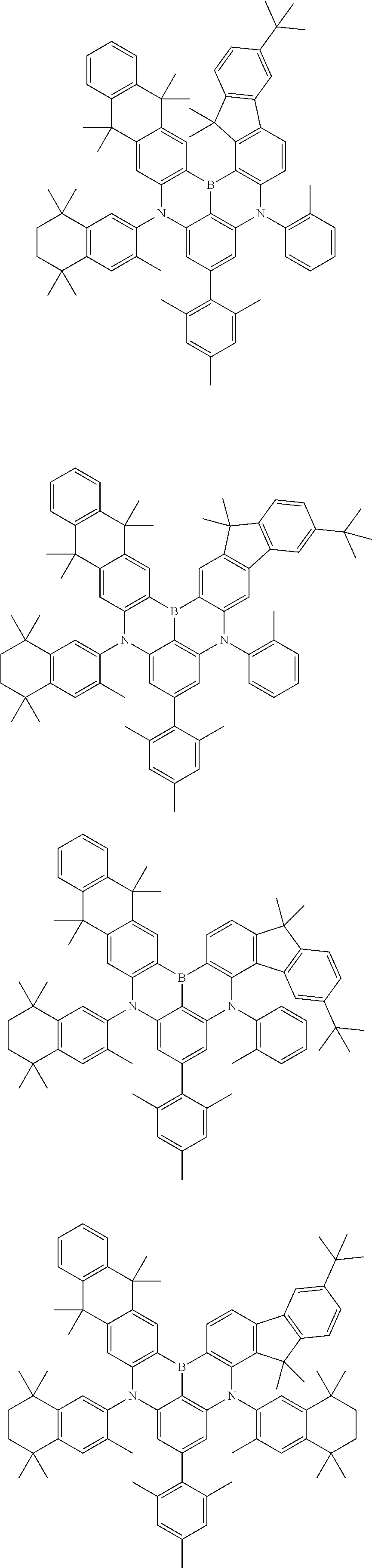

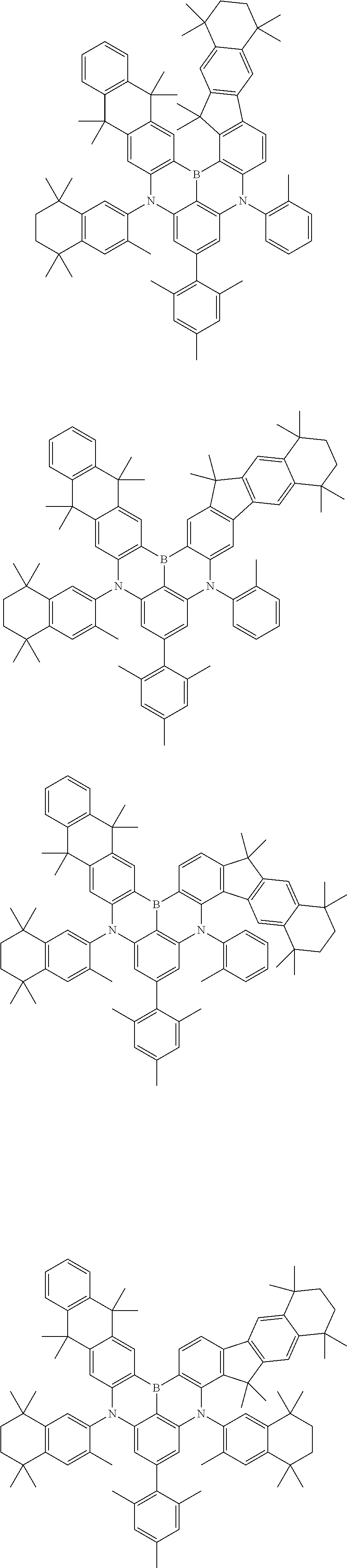

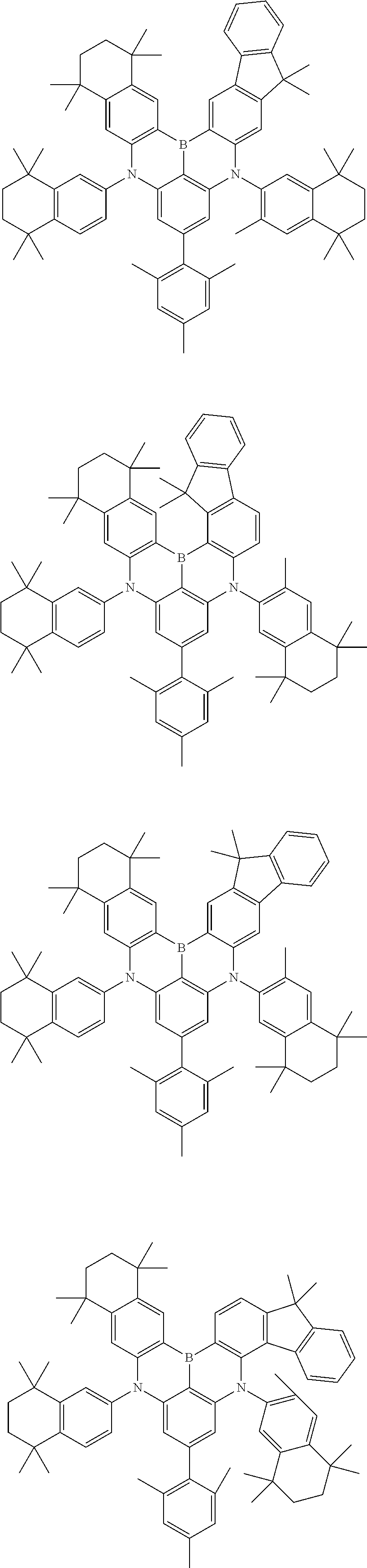

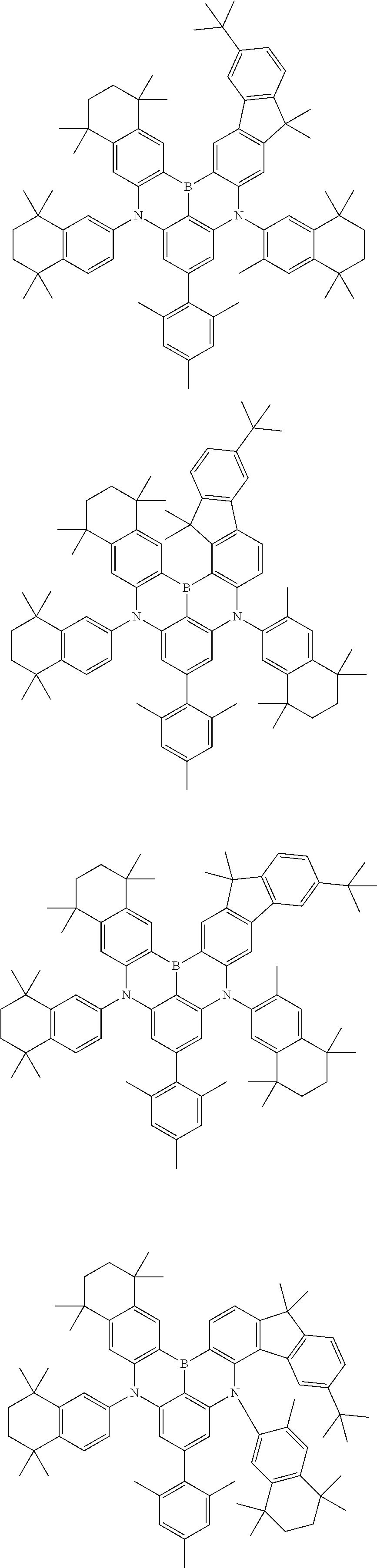

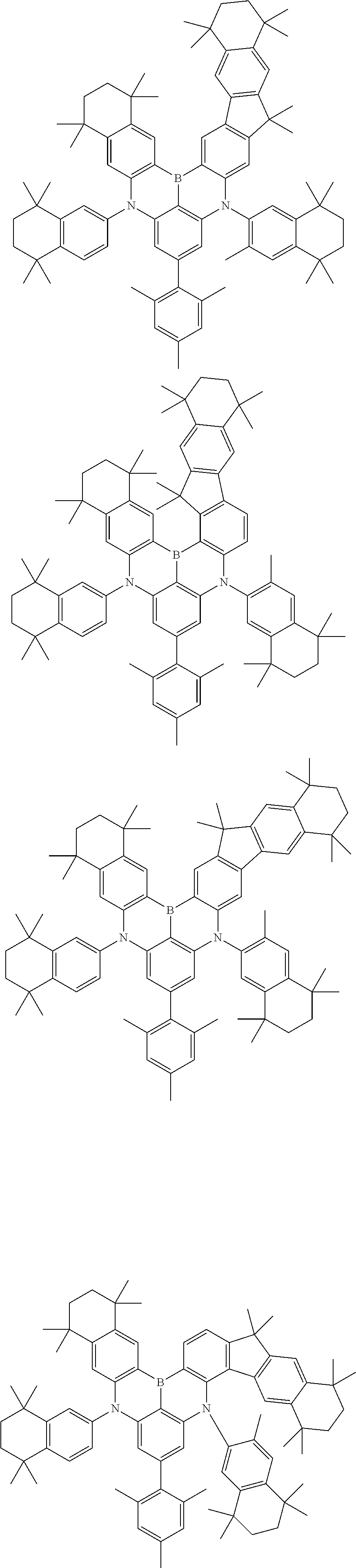

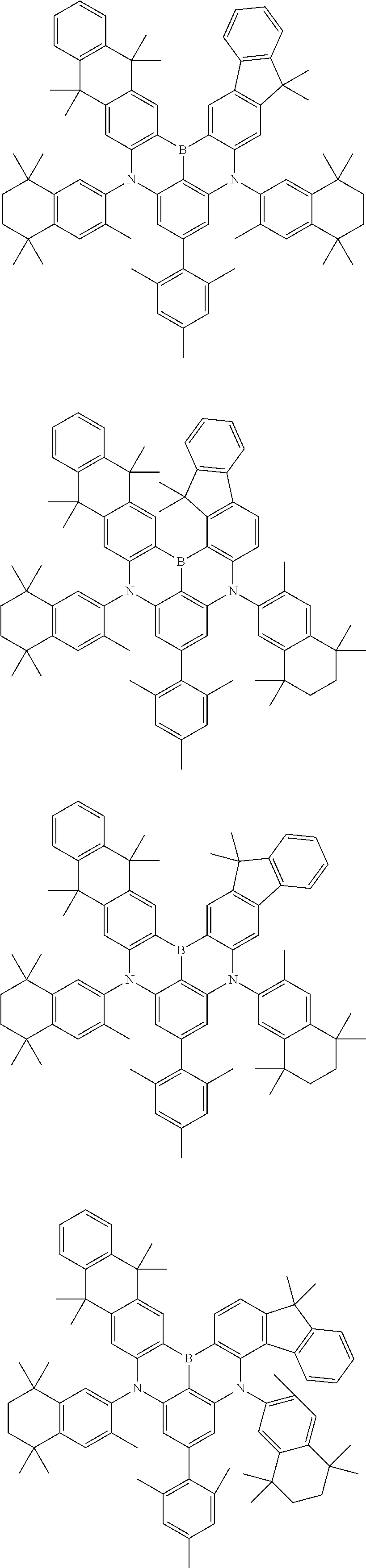

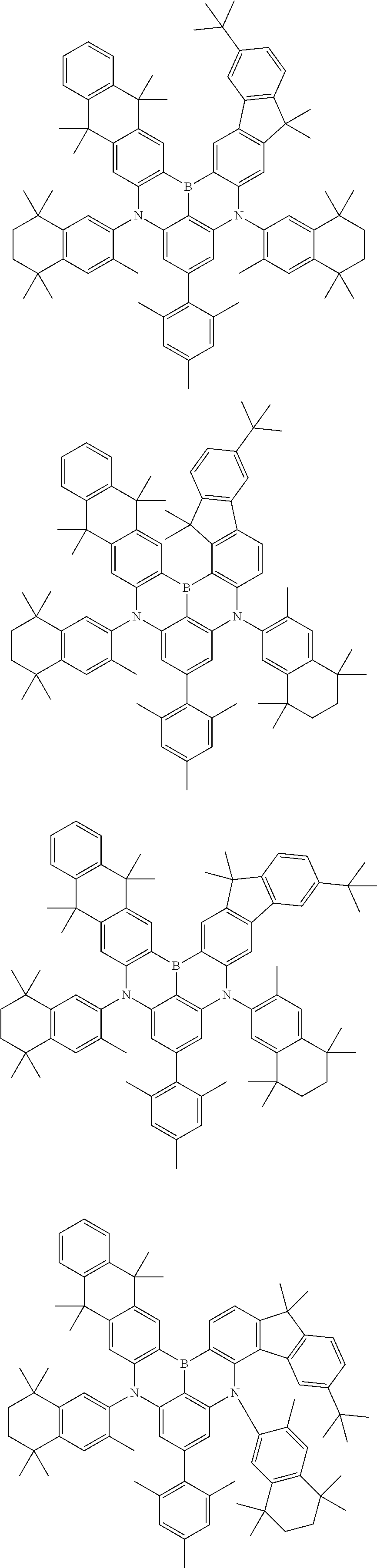

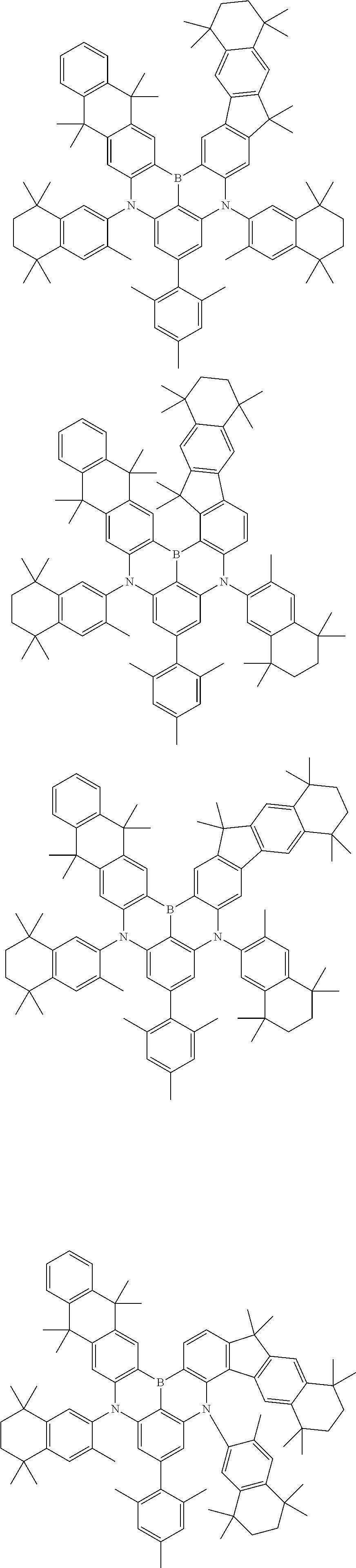

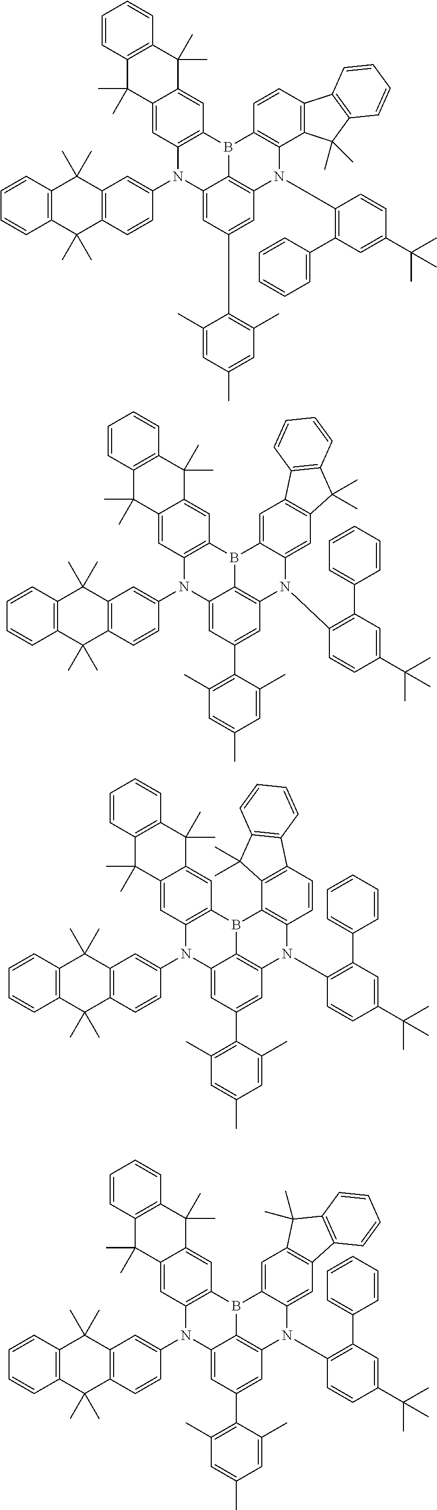

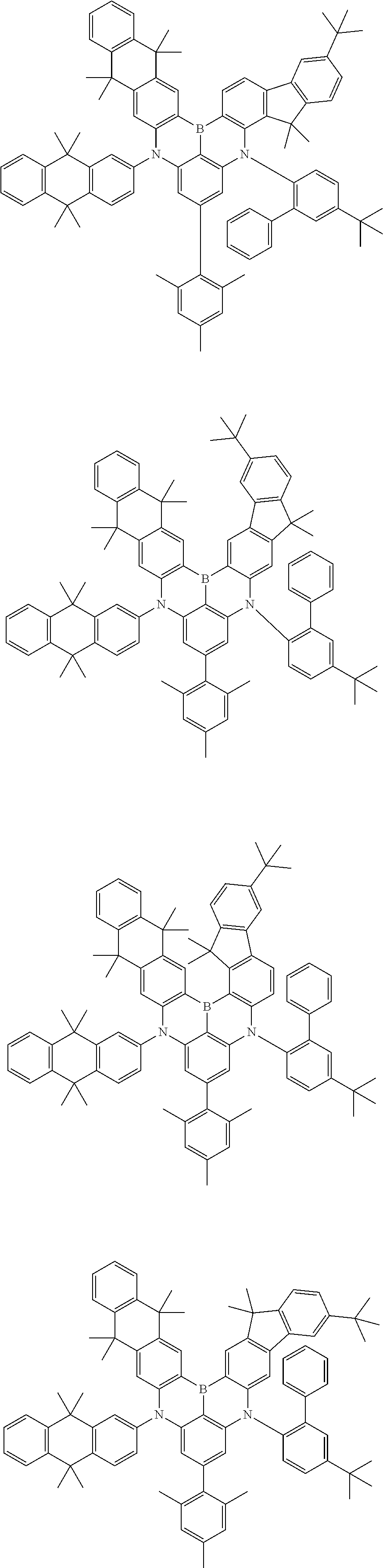

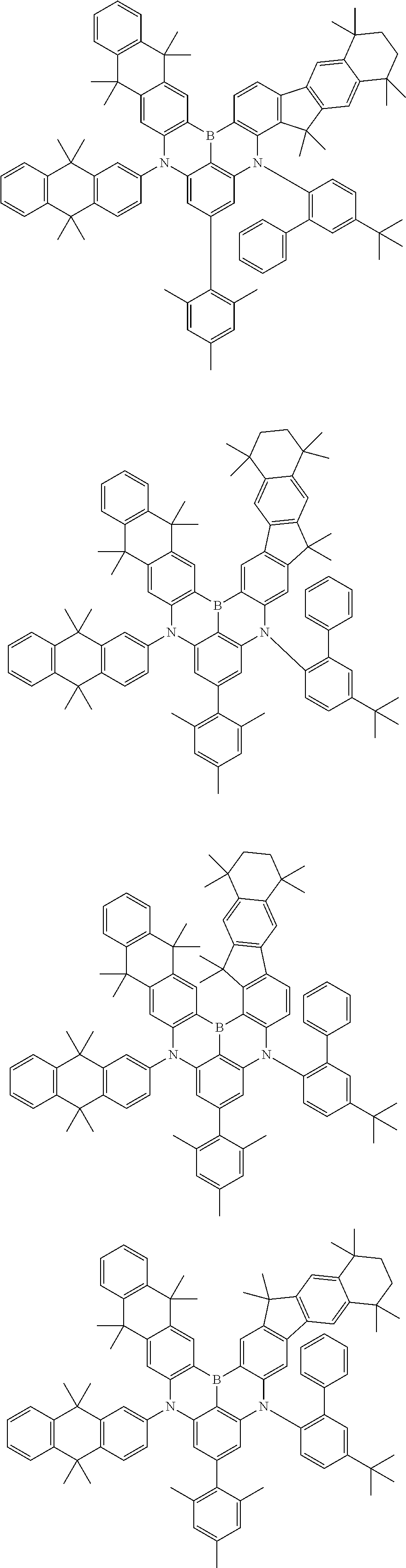

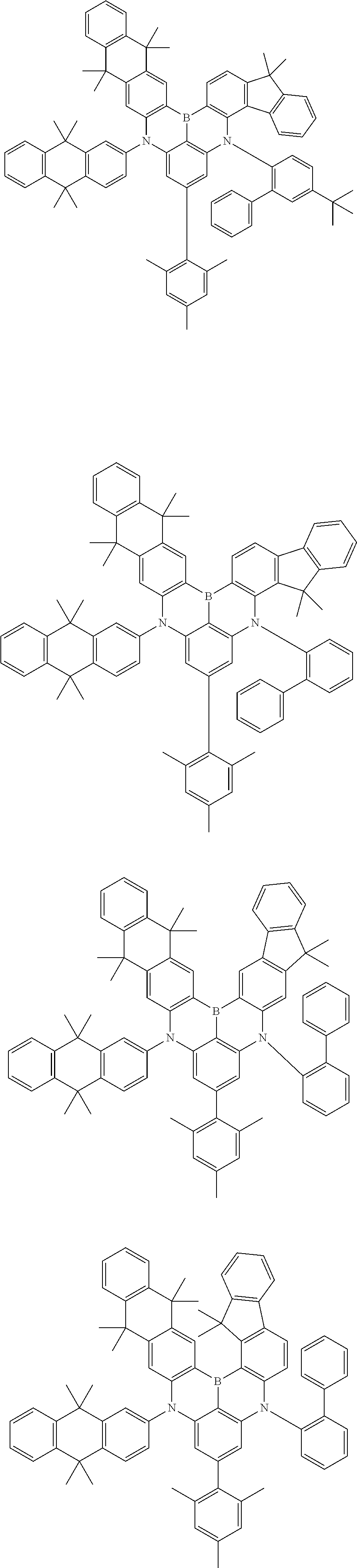

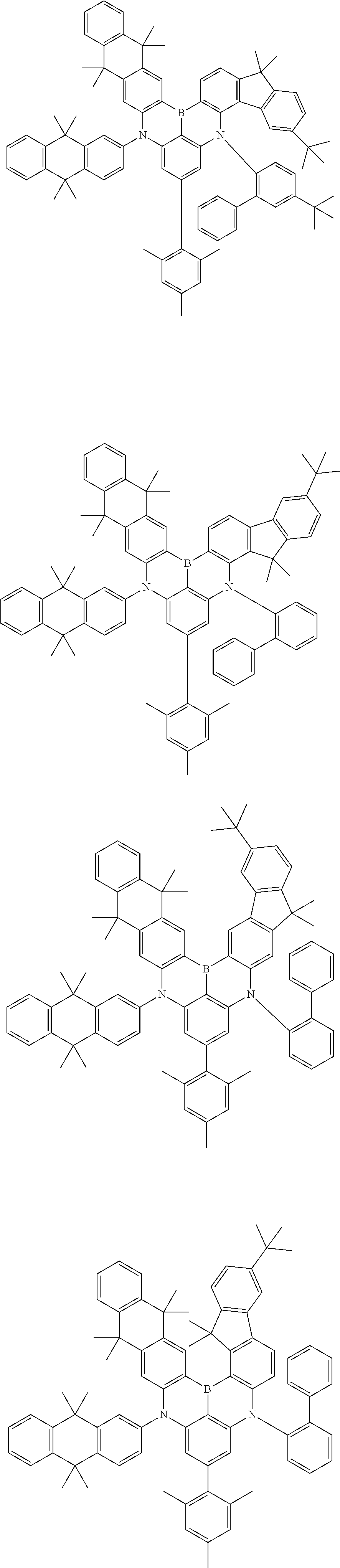

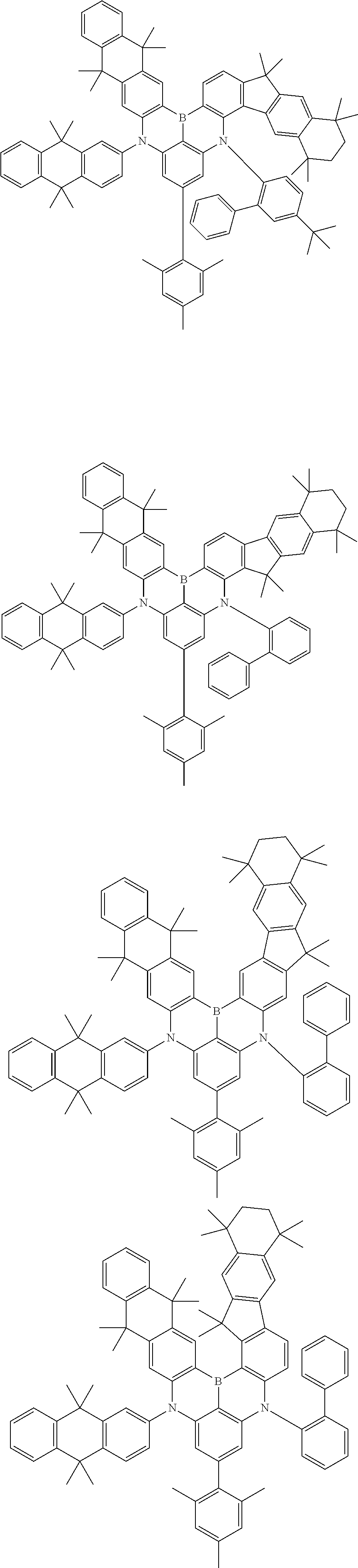

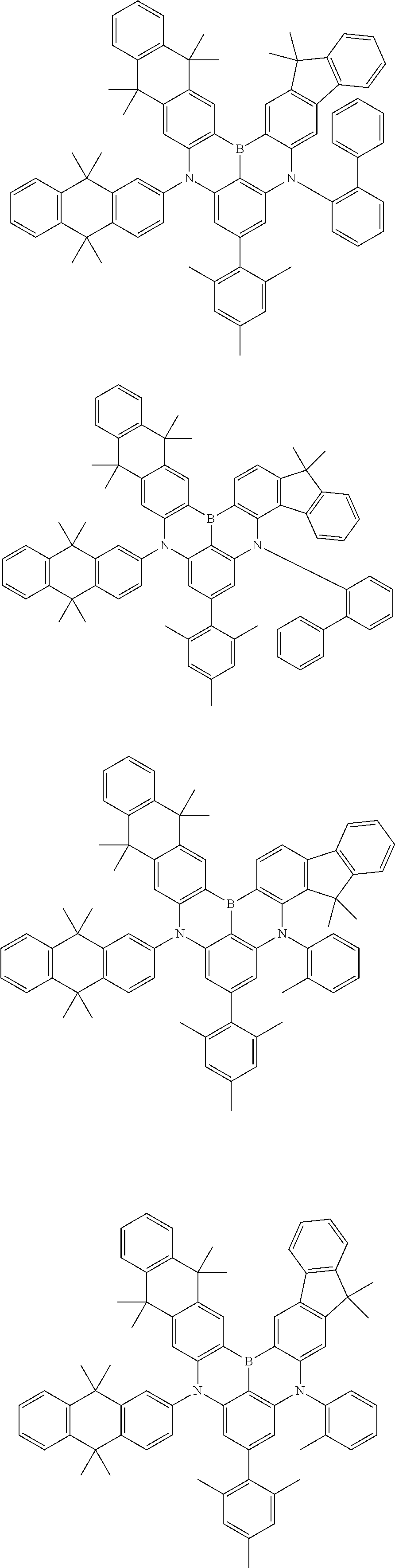

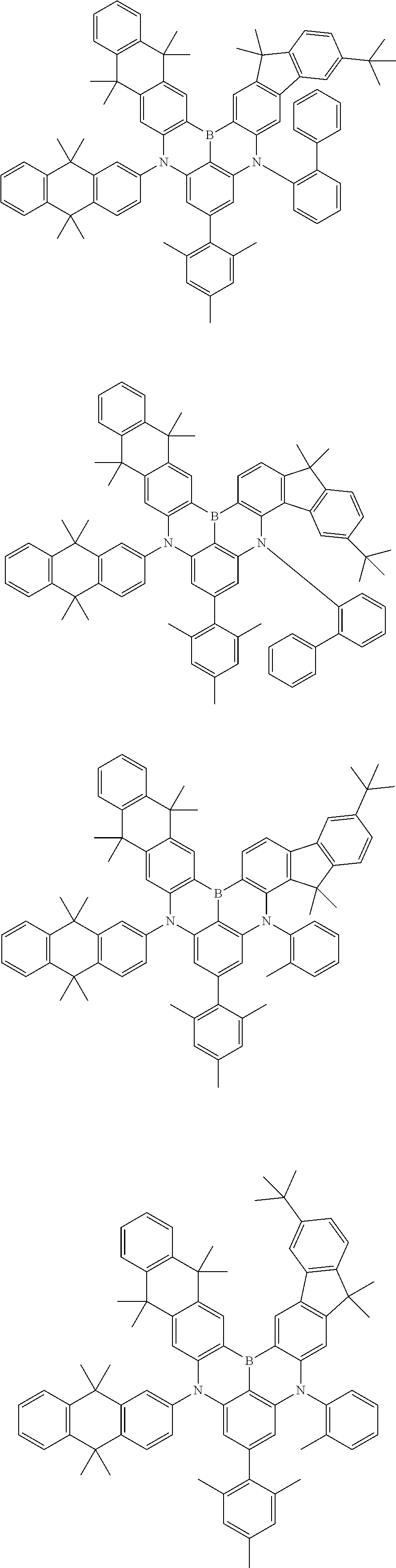

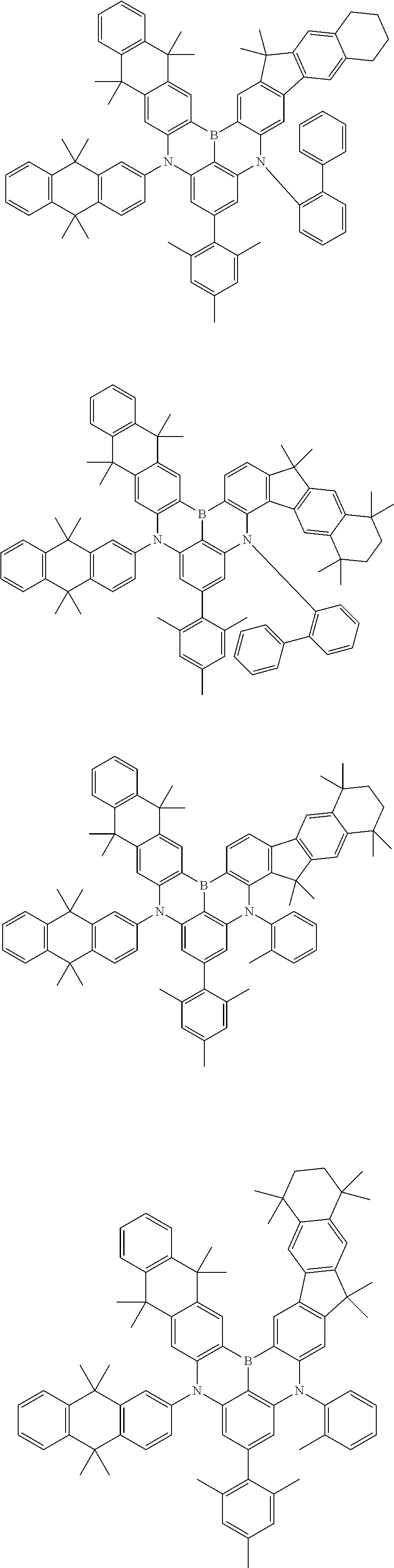

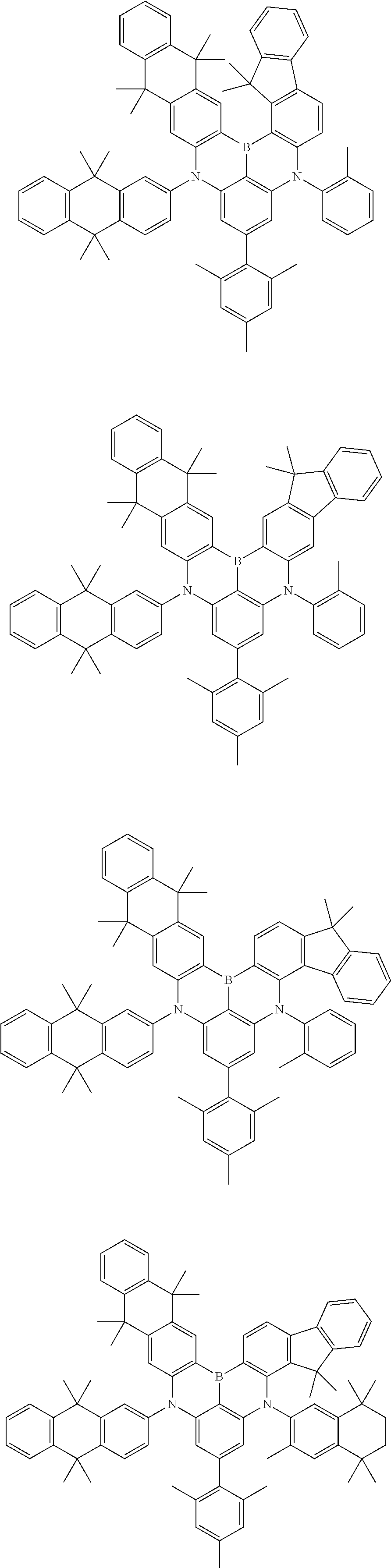

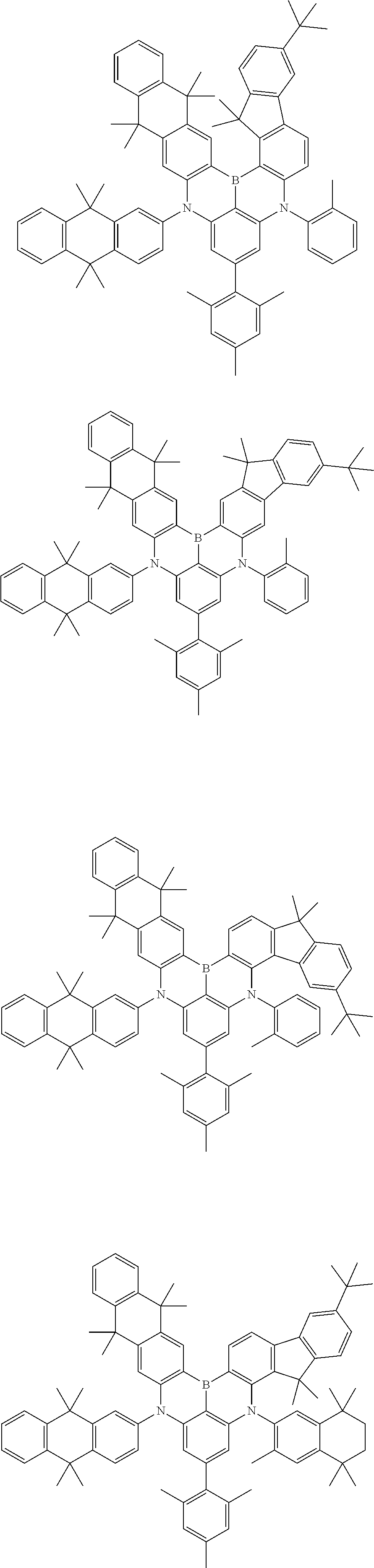

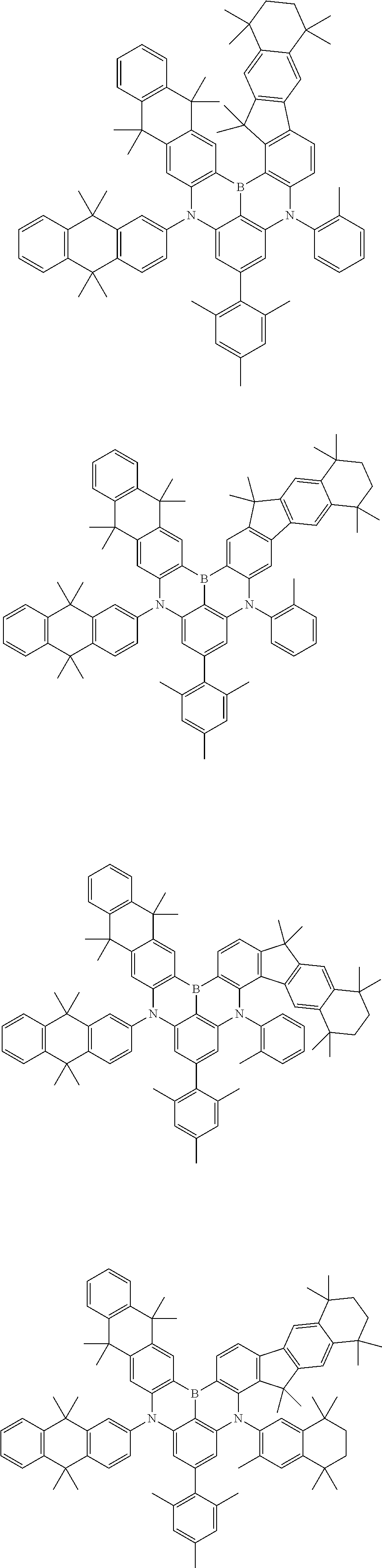

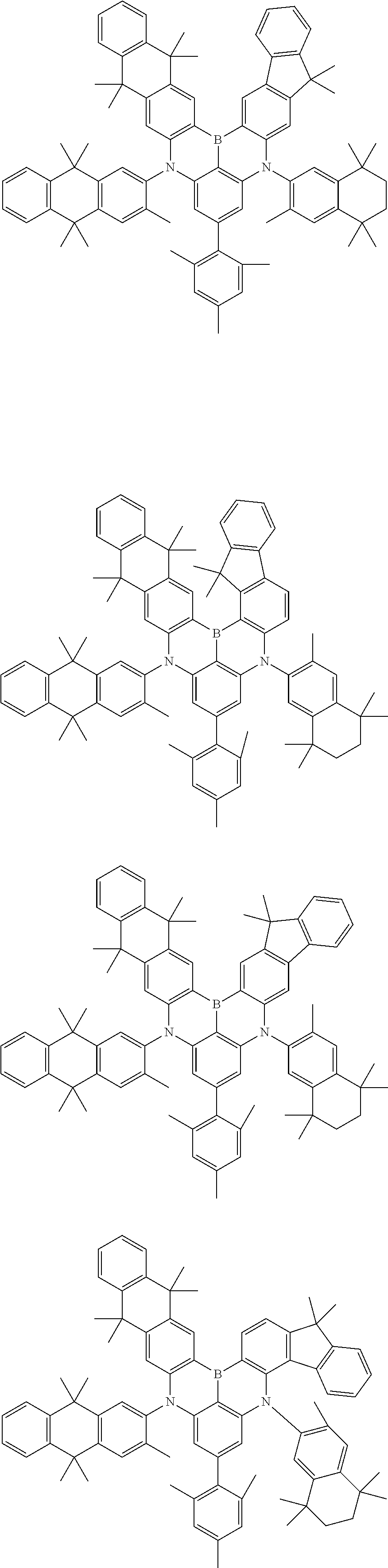

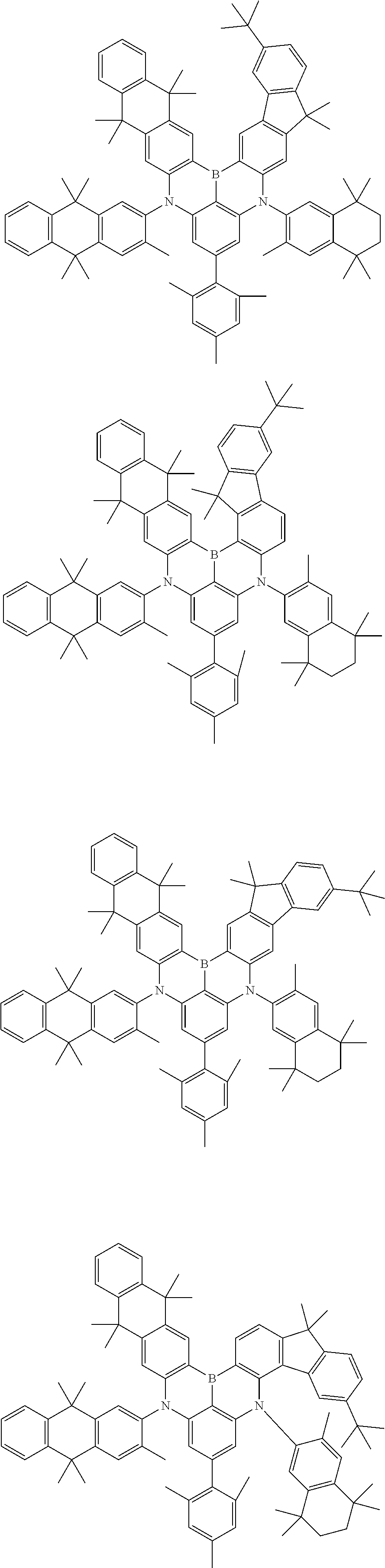

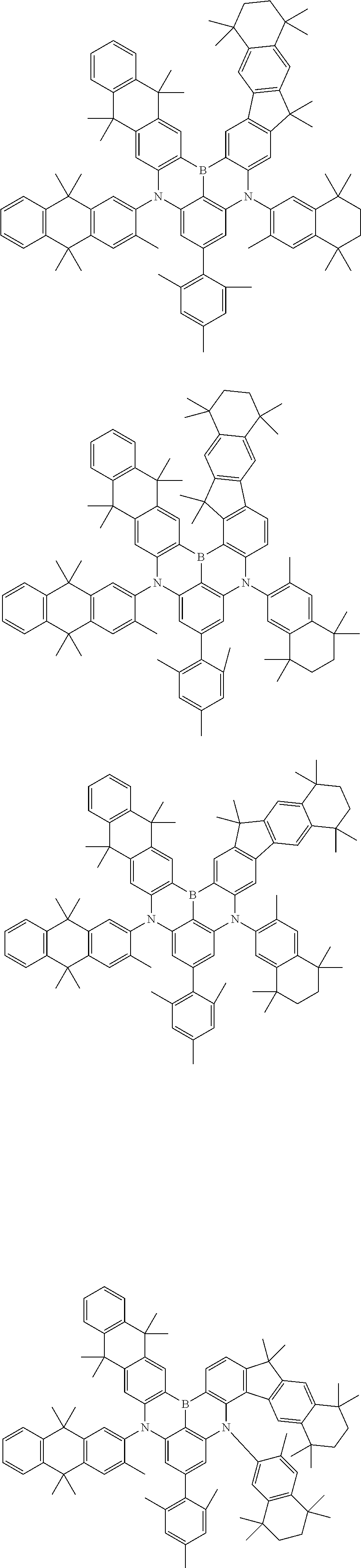

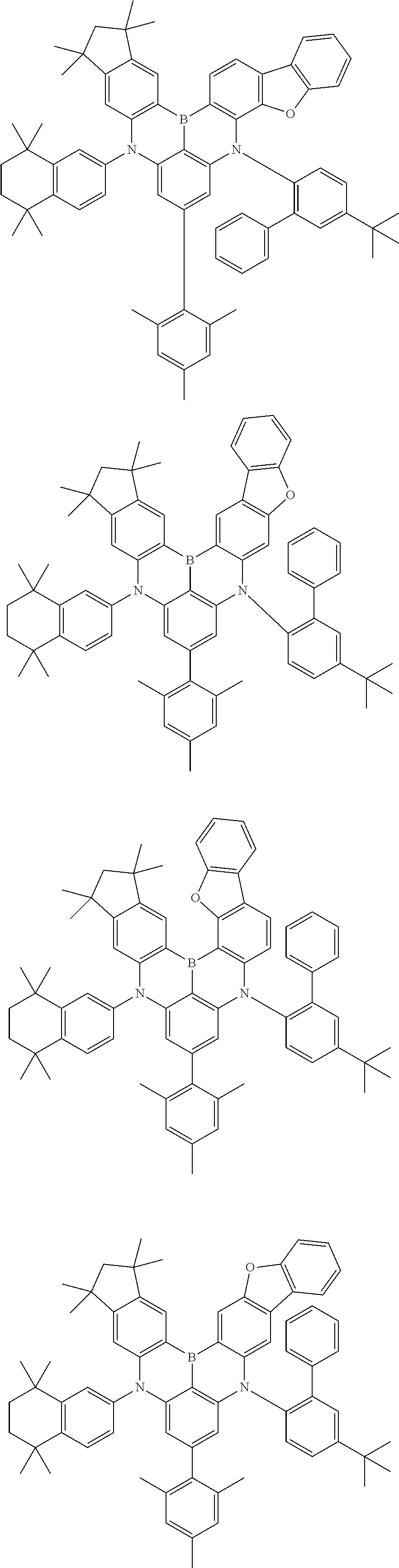

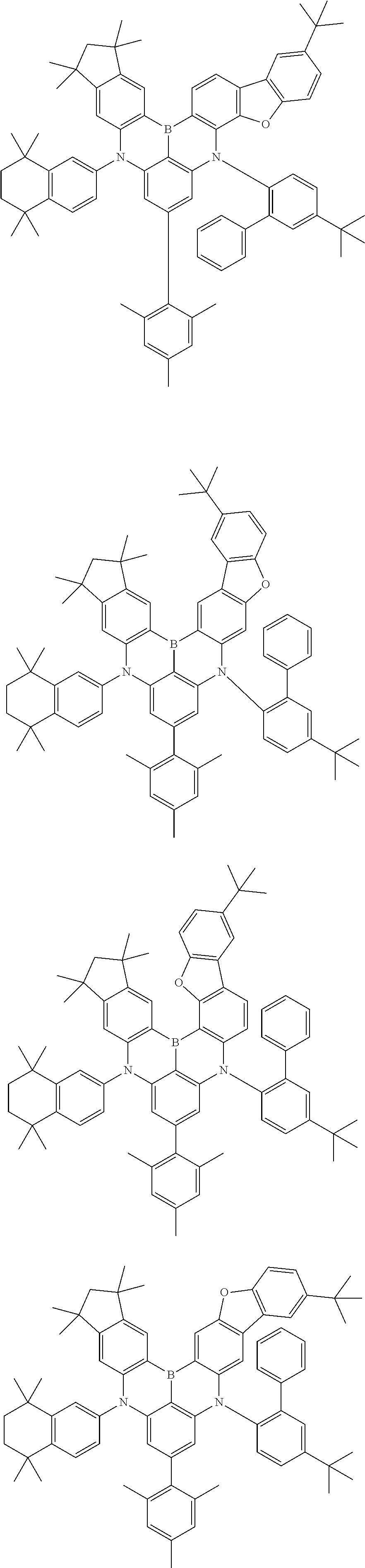

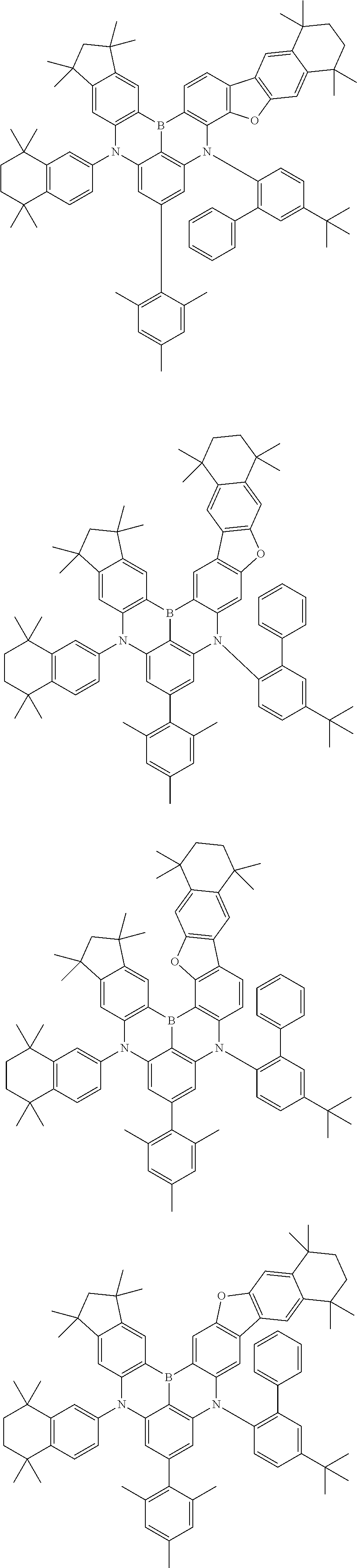

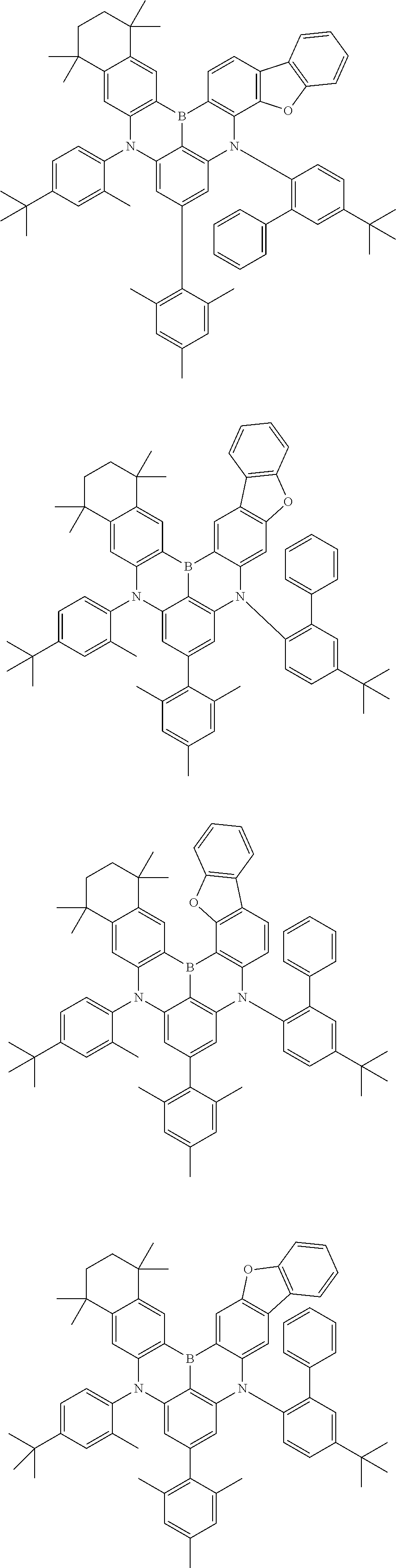

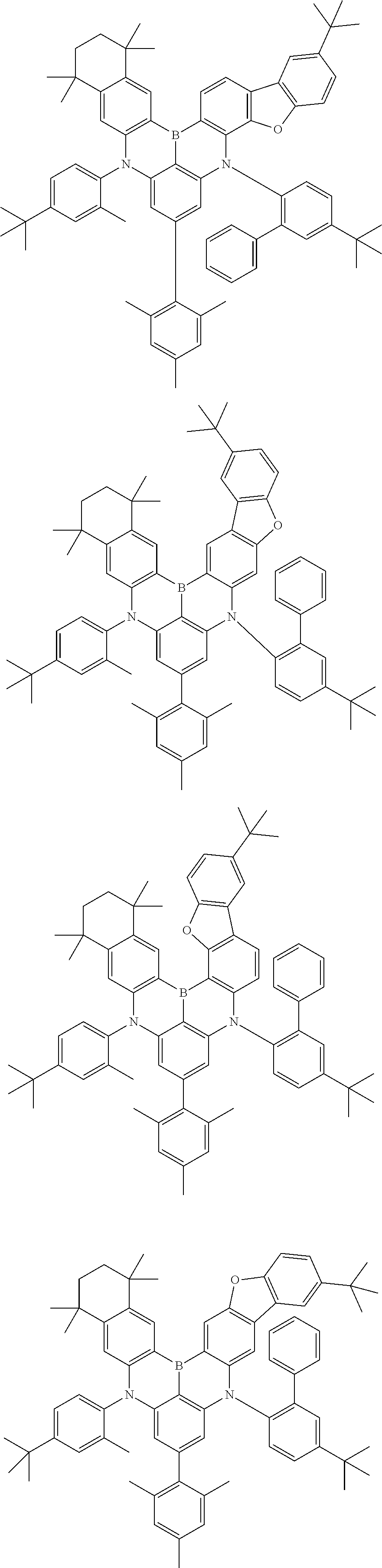

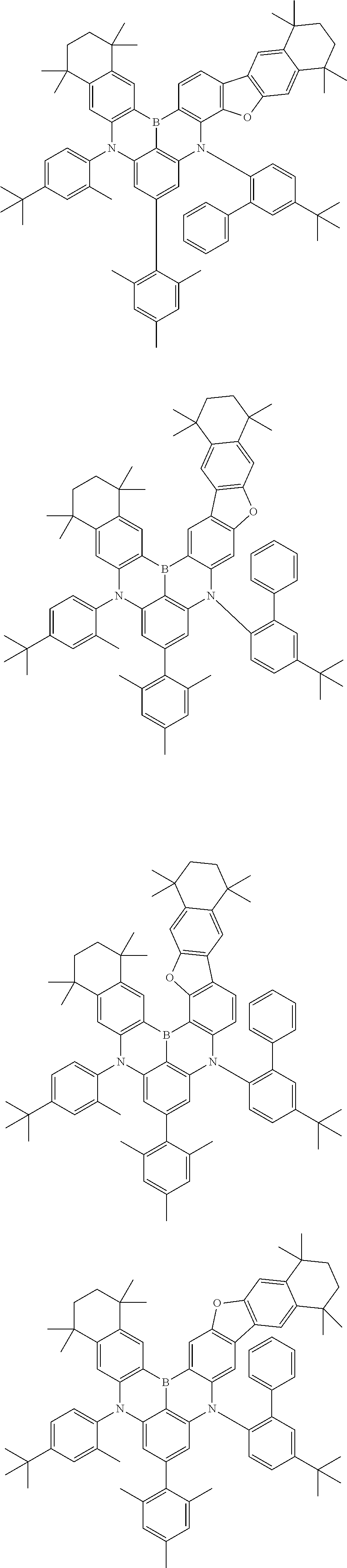

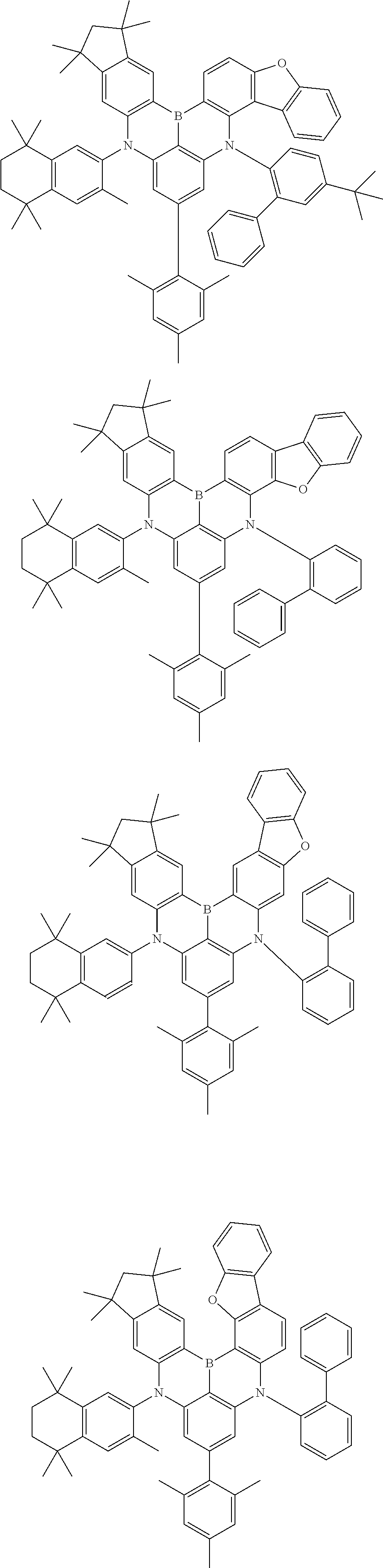

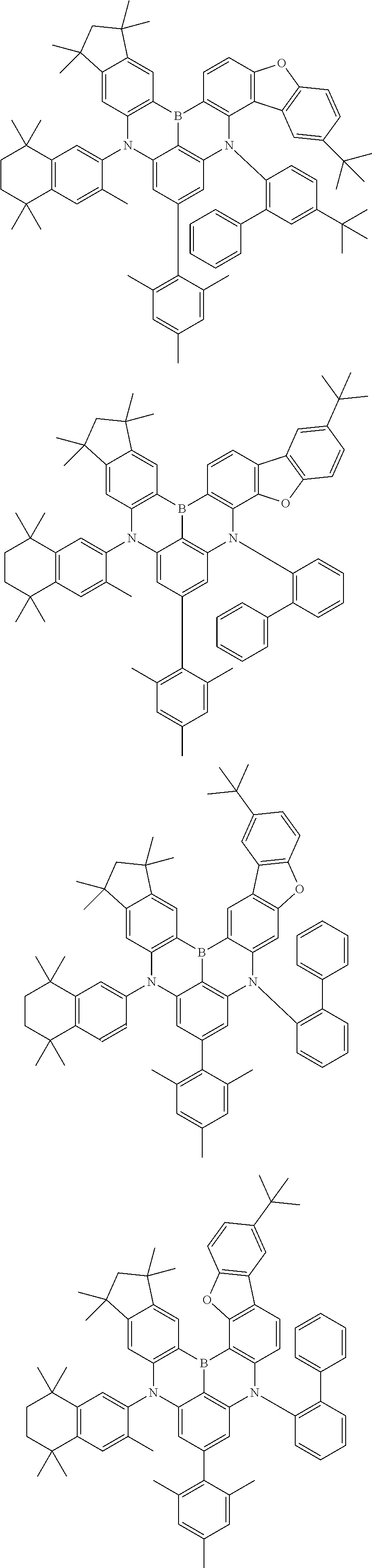

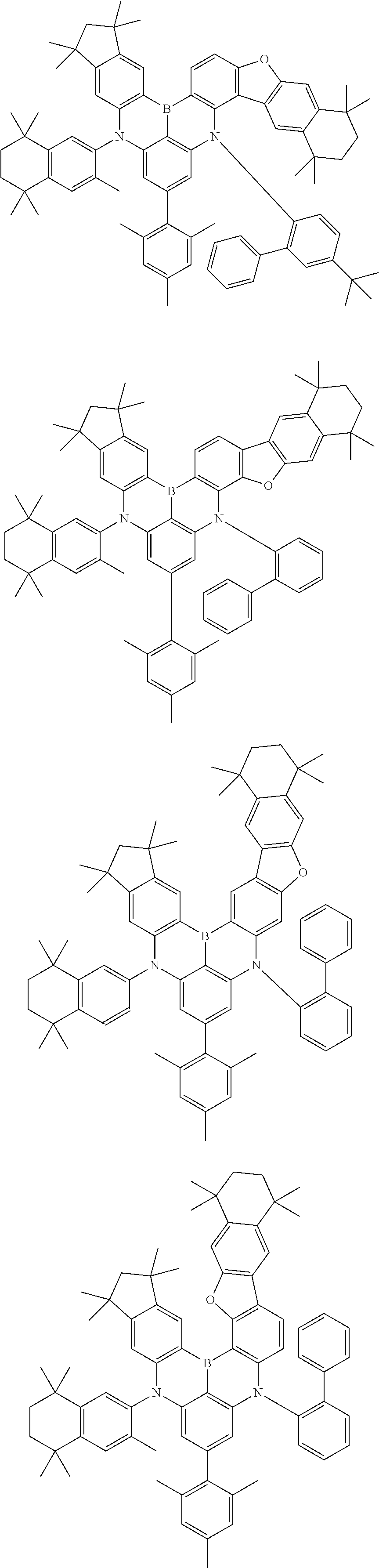

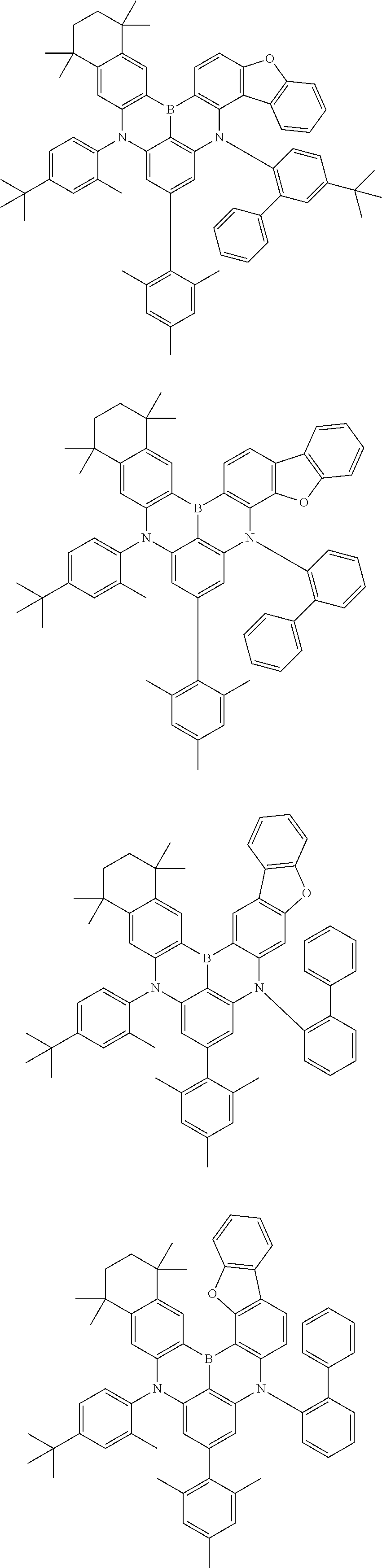

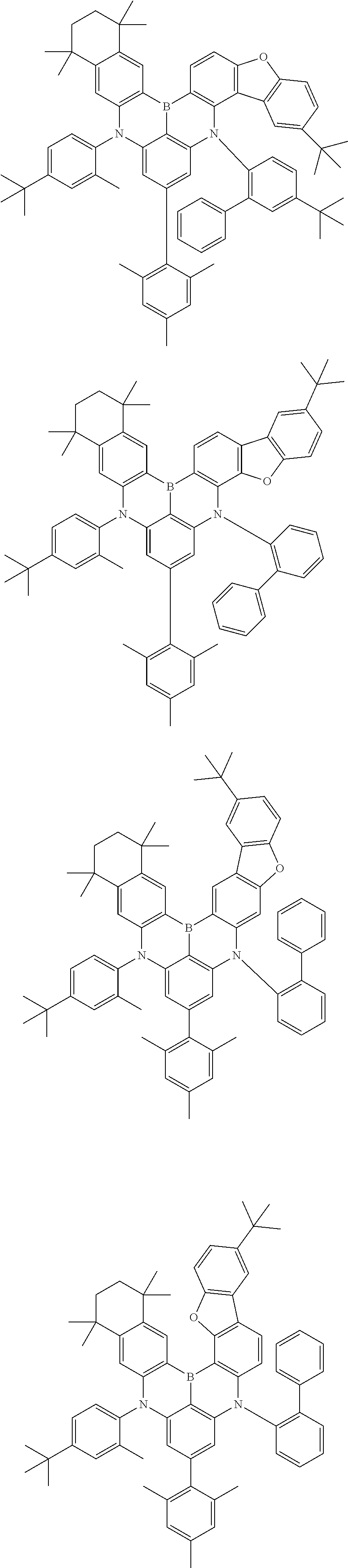

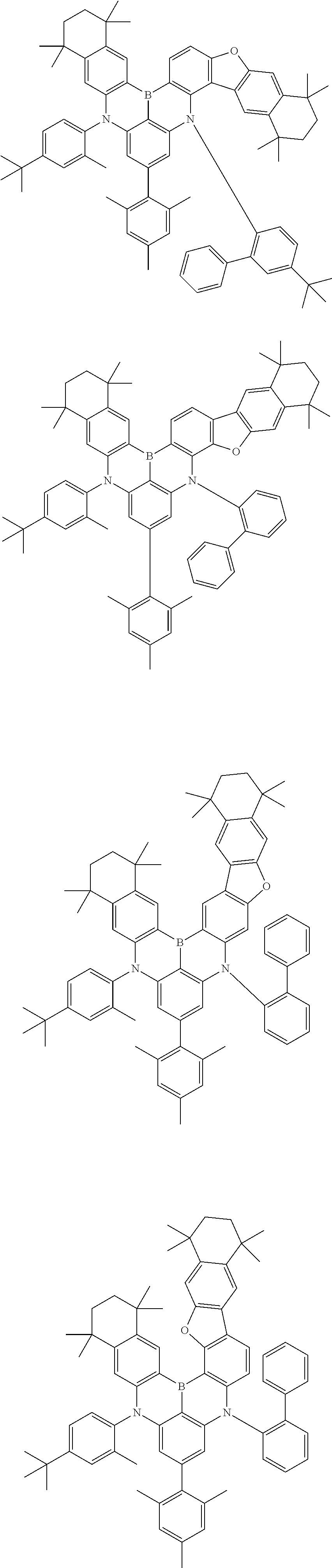

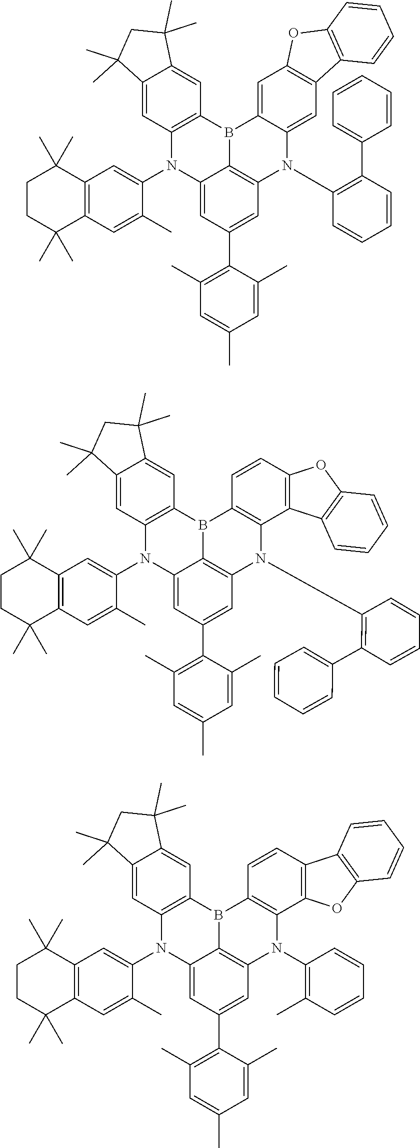 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2oc2ccccc25)B4c2cc4c(cc2N3c2cc3c(cc2C)C(C)(C)CCC3(C)C)C(C)(C)CC4(C)C)c(C)c1]

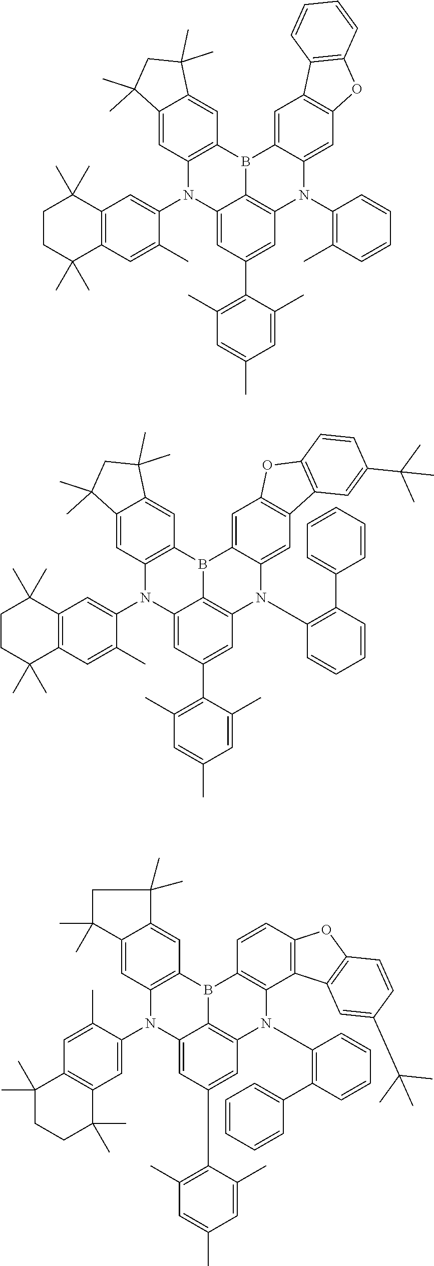

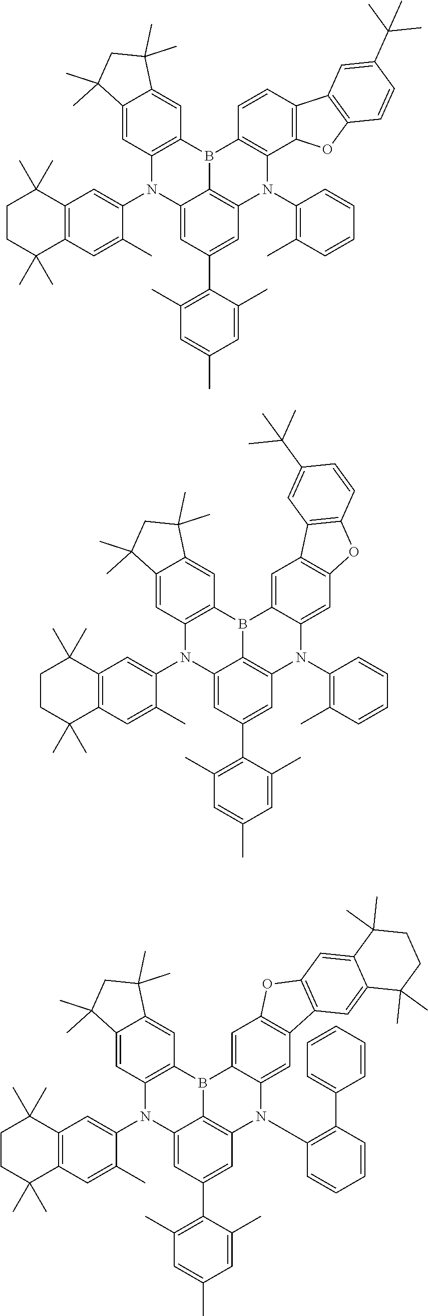 [SMILES: Cc1cc(C)c(-c2cc3c4c(c2)N(c2ccccc2C)c2c(ccc5c2oc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5oc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)oc2cc3c(cc25)C(C)(C)CCC3(C)C)c(C)c1]

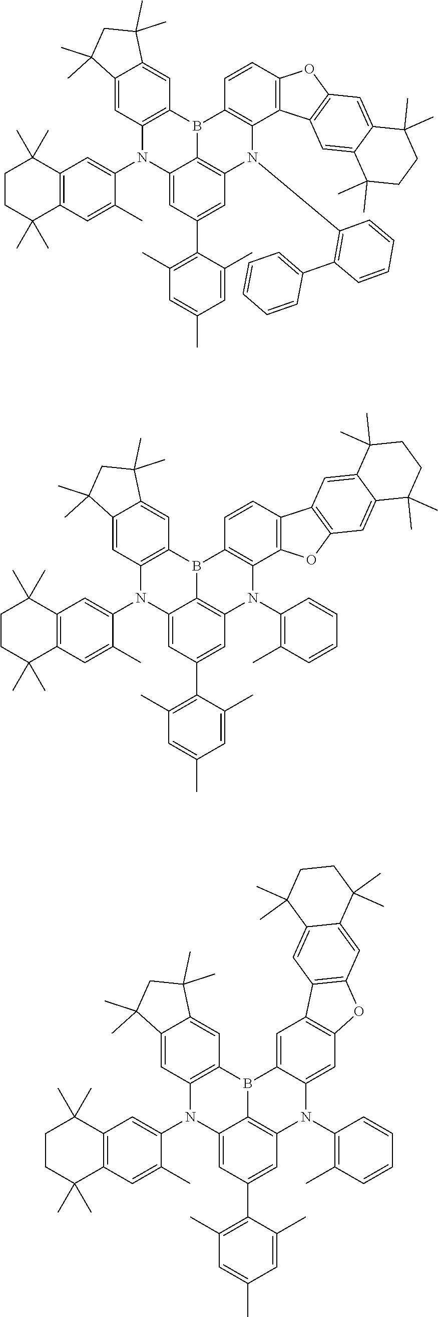 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5oc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

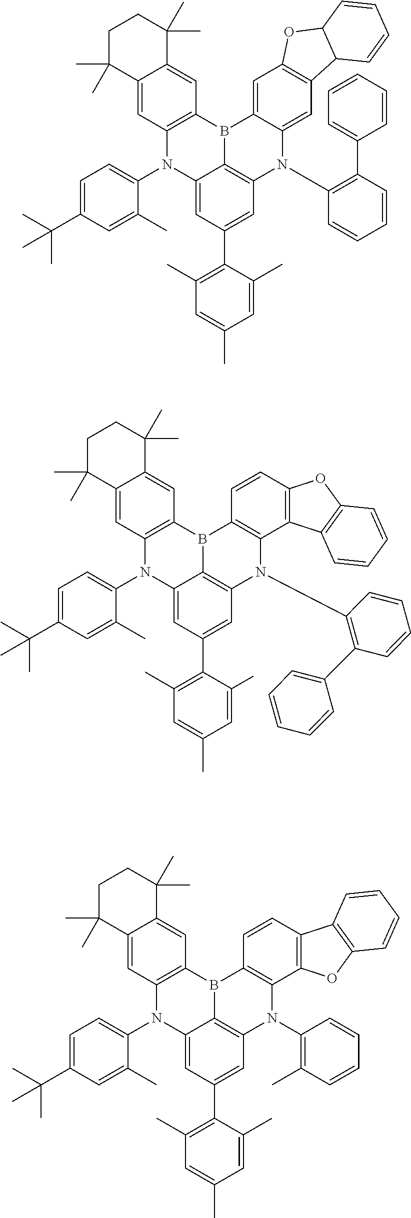 [SMILES: Cc1cc(C)c(-c2cc3c4c(c2)N(c2ccccc2-c2ccccc2)c2cc5c(cc2B4c2cc4c(cc2N3c2ccc(C(C)(C)C)cc2C)C(C)(C)CCC4(C)C)OC2C=CC=CC52)c(C)c1 ; Cc1cc(C)c(-c2cc3c4c(c2)N(c2ccccc2-c2ccccc2)c2c(ccc5oc6ccccc6c25)B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2c(ccc5c2oc2ccccc25)B4c2cc4c(cc2N3c2ccc(C(C)(C)C)cc2C)C(C)(C)CCC4(C)C)c(C)c1]

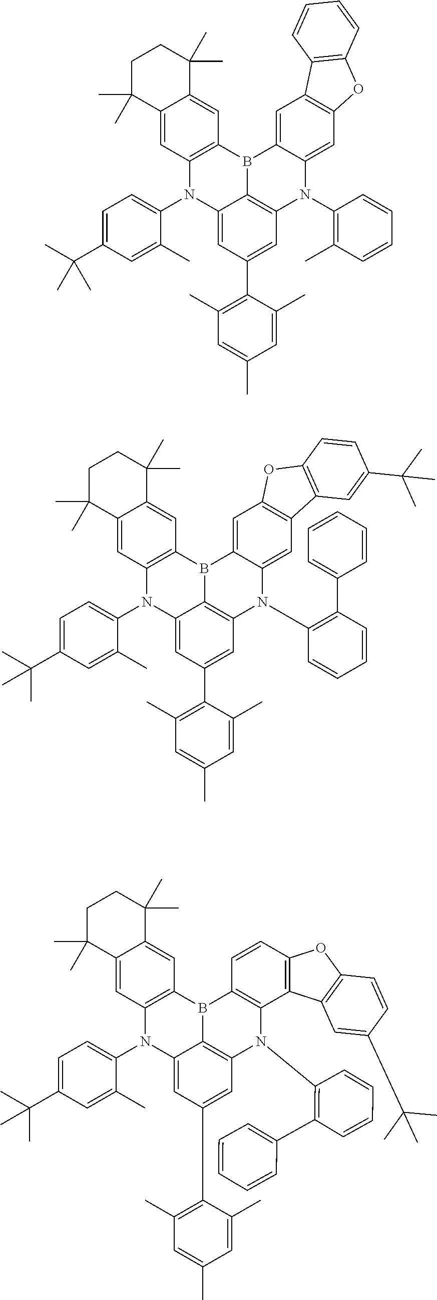

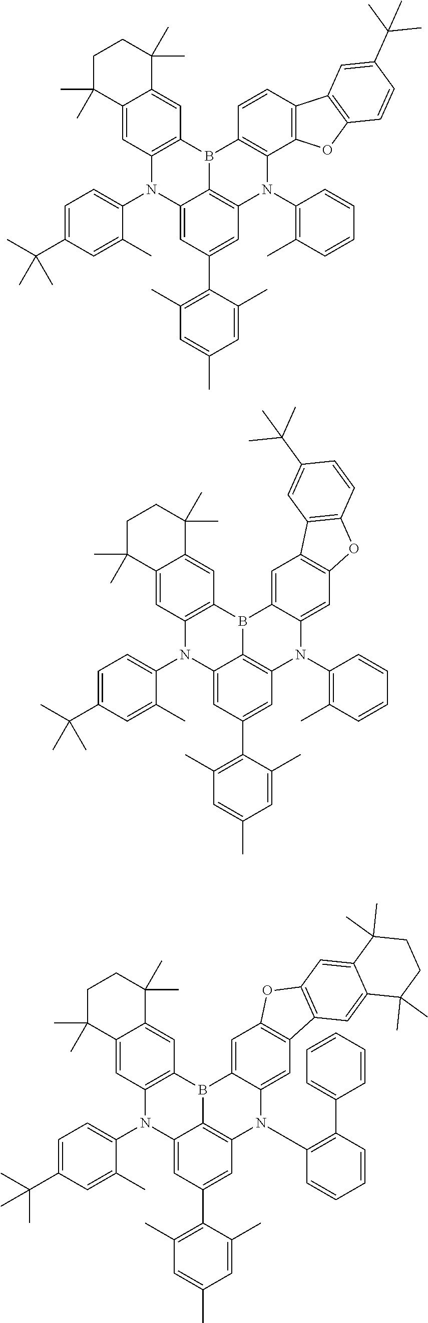

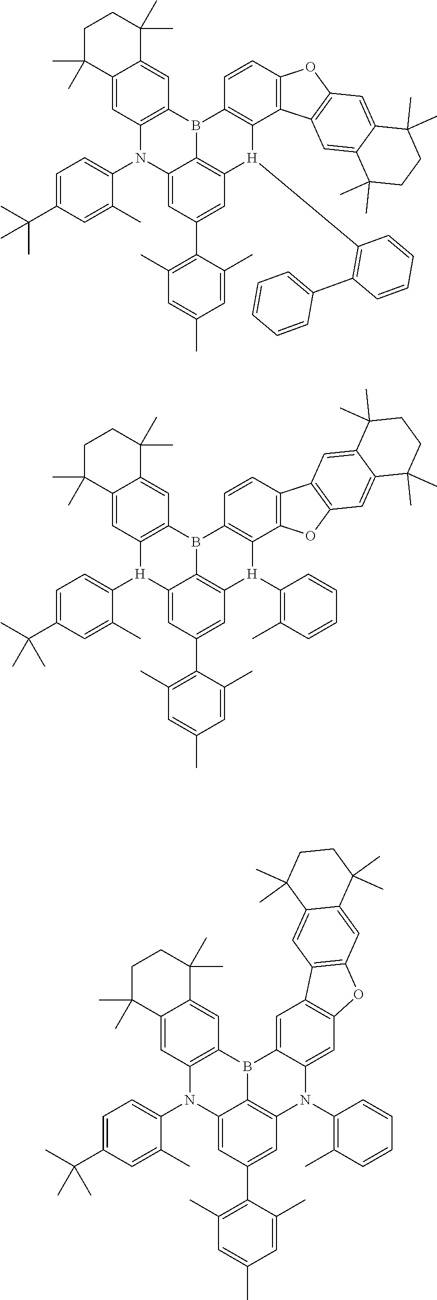

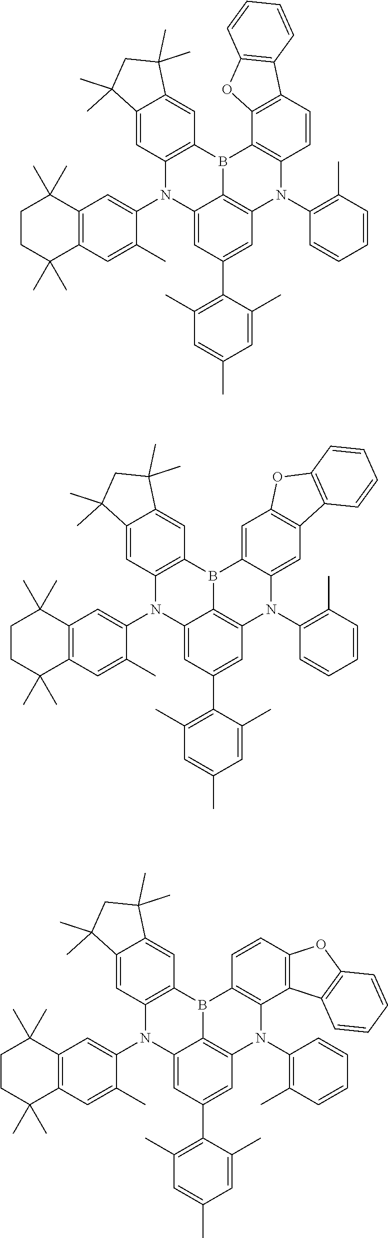 [SMILES: Cc1cc(C)c(-c2cc3c4c(c2)N(c2ccccc2C)c2ccc5c(oc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2cc3c(cc2C)C(C)(C)CCC3(C)C)C(C)(C)CC4(C)C)c(C)c1]

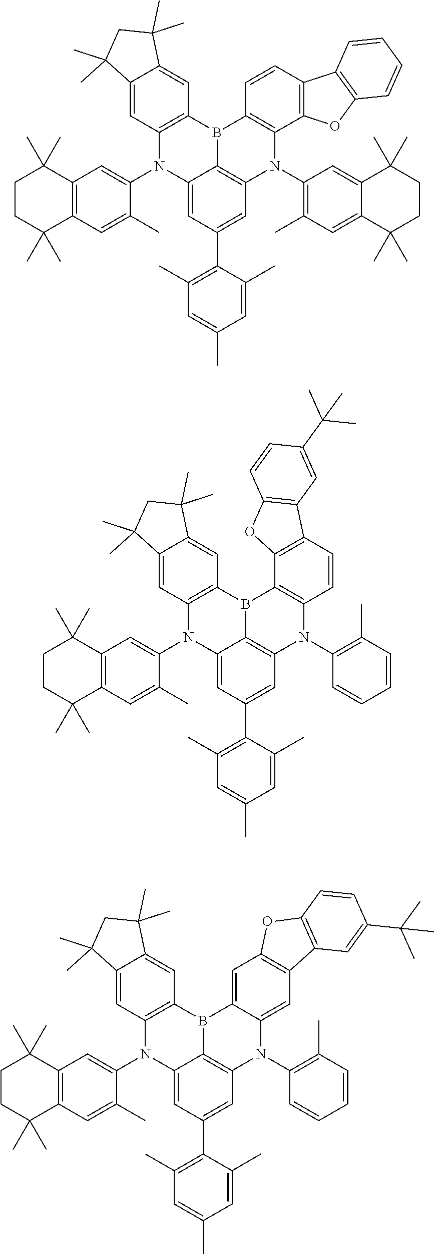 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)oc2ccc(C(C)(C)C)cc25)c(C)c1]

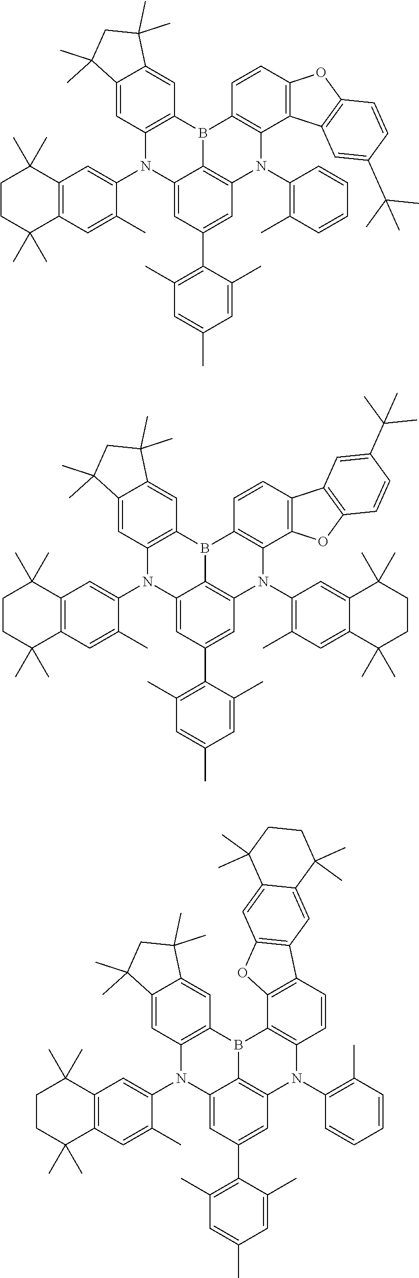 [SMILES: Cc1cc(C)c(-c2cc3c4c(c2)N(c2ccccc2C)c2c(ccc5oc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2oc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(oc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

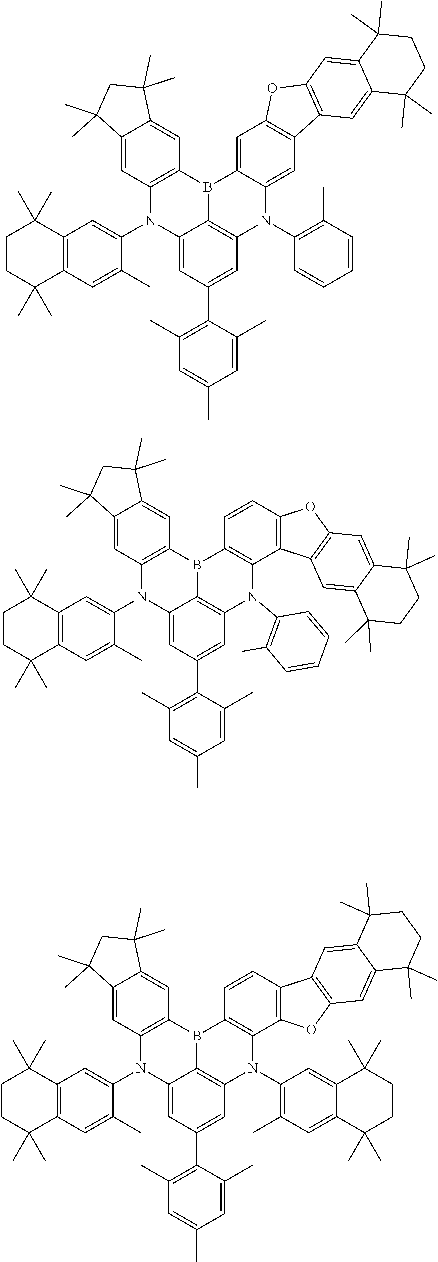 [SMILES: Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

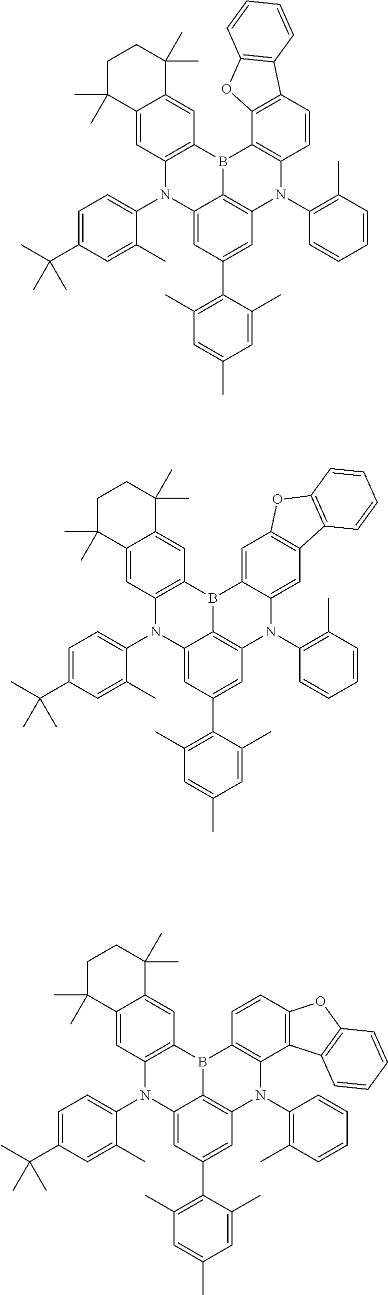 [SMILES: Cc1cc(C)c(-c2cc3c4c(c2)N(c2ccccc2C)c2ccc5c(oc6ccccc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2ccc(C(C)(C)C)cc2C)C(C)(C)CCC4(C)C)c(C)c1]

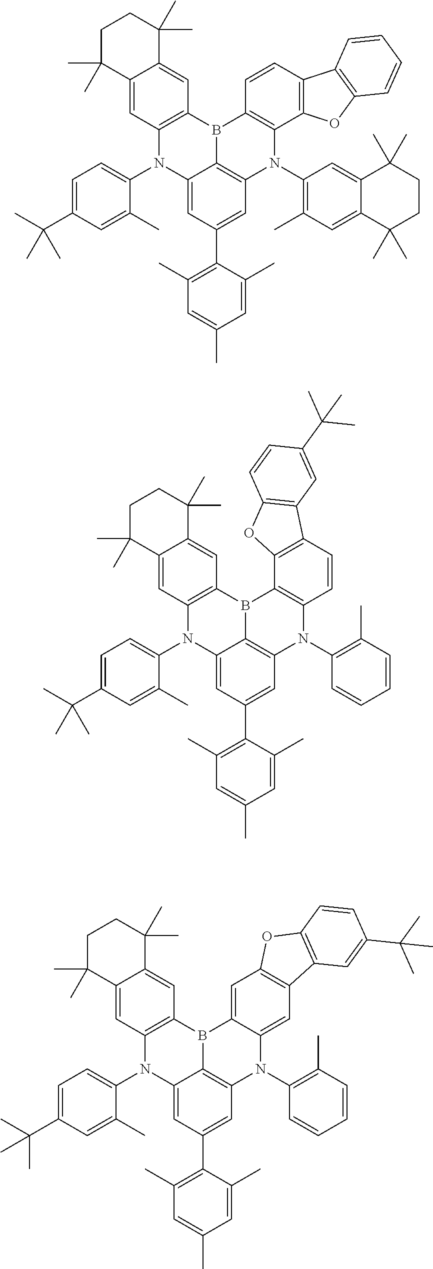 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)oc2ccc(C(C)(C)C)cc25)c(C)c1]

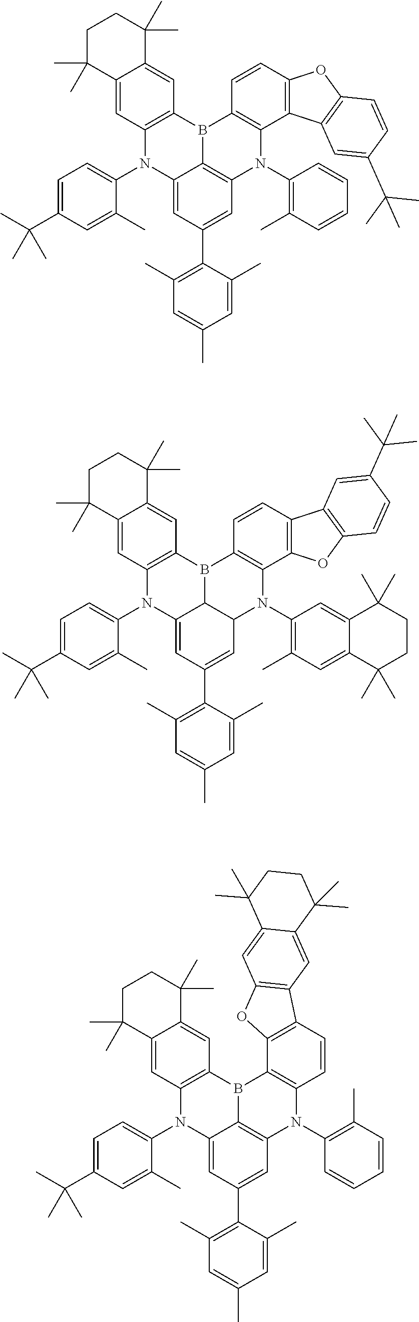

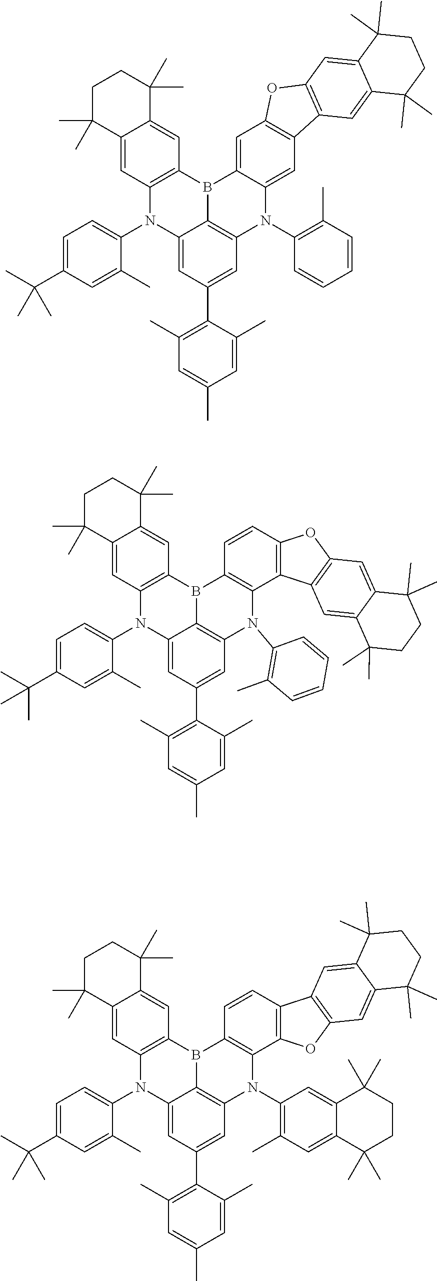

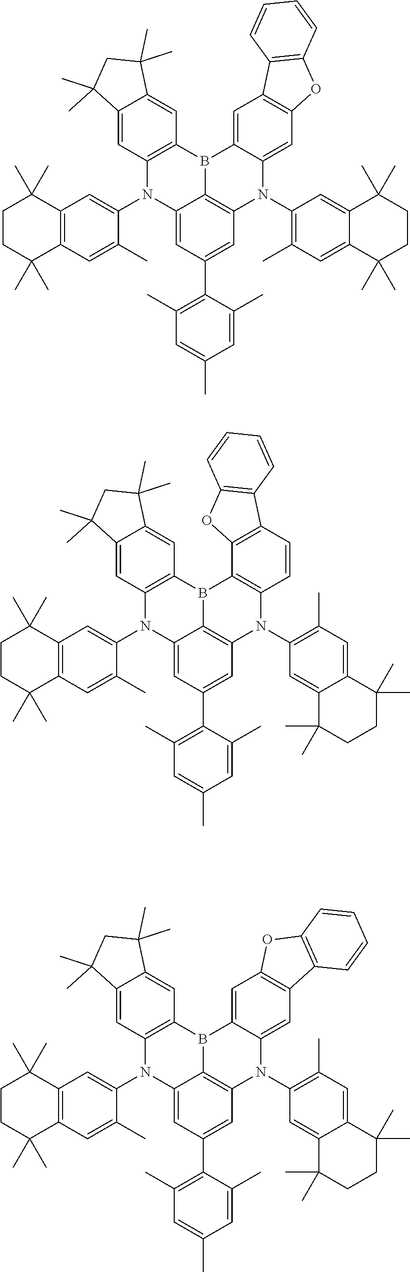

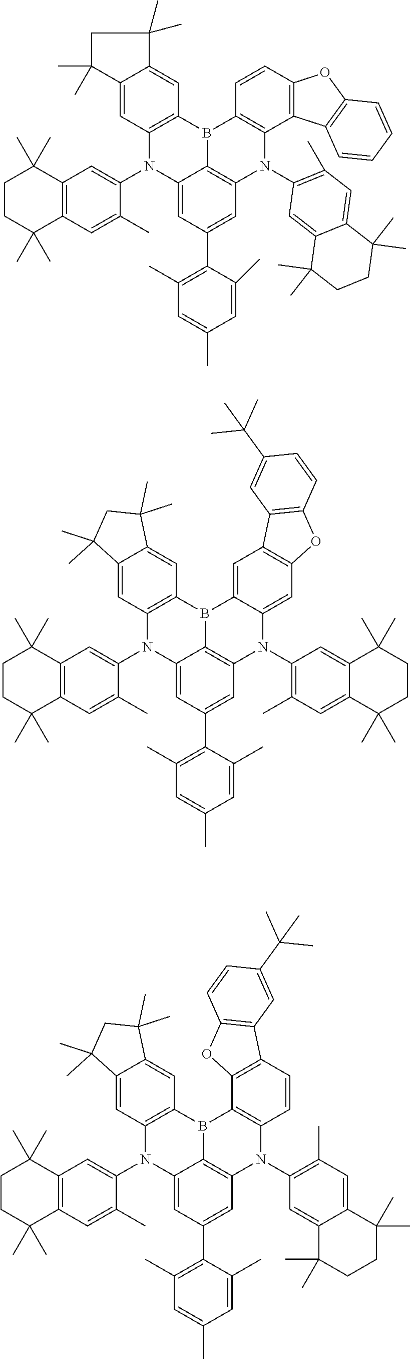

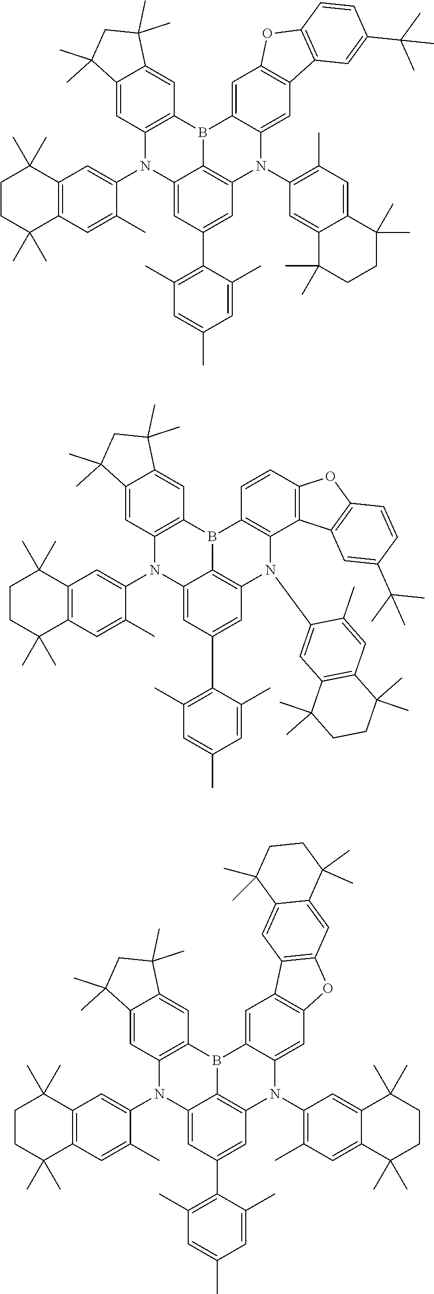 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

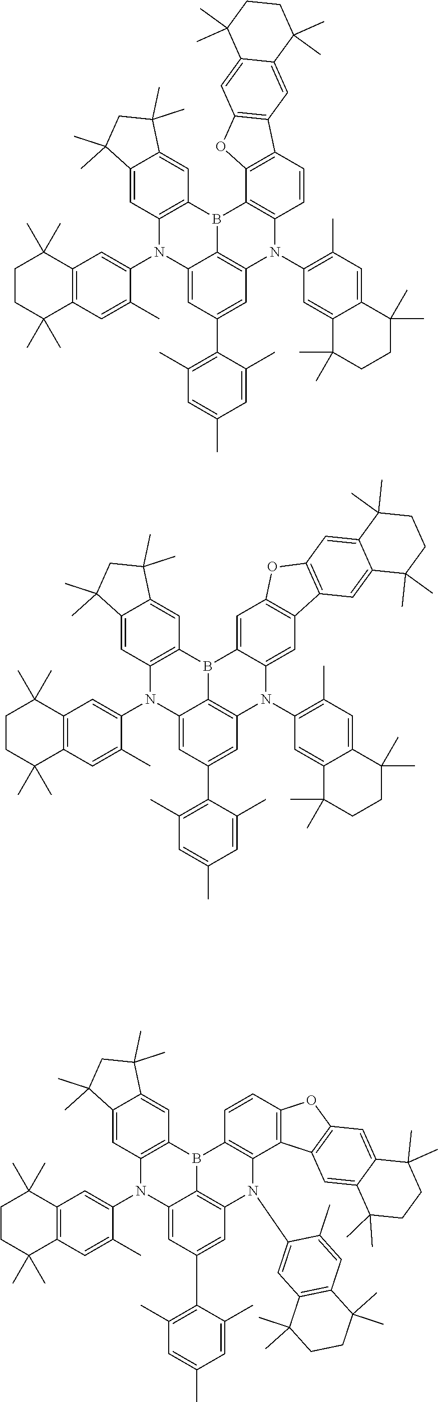 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1]

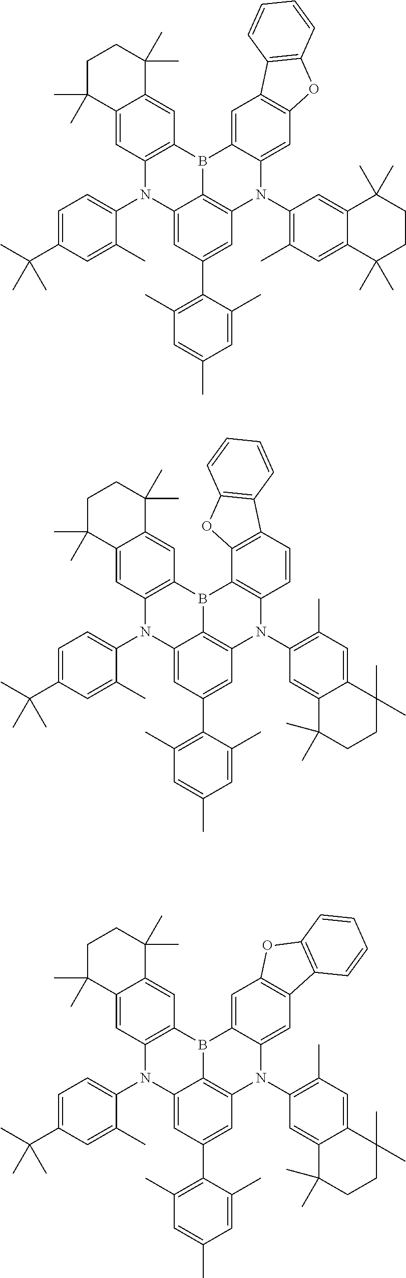

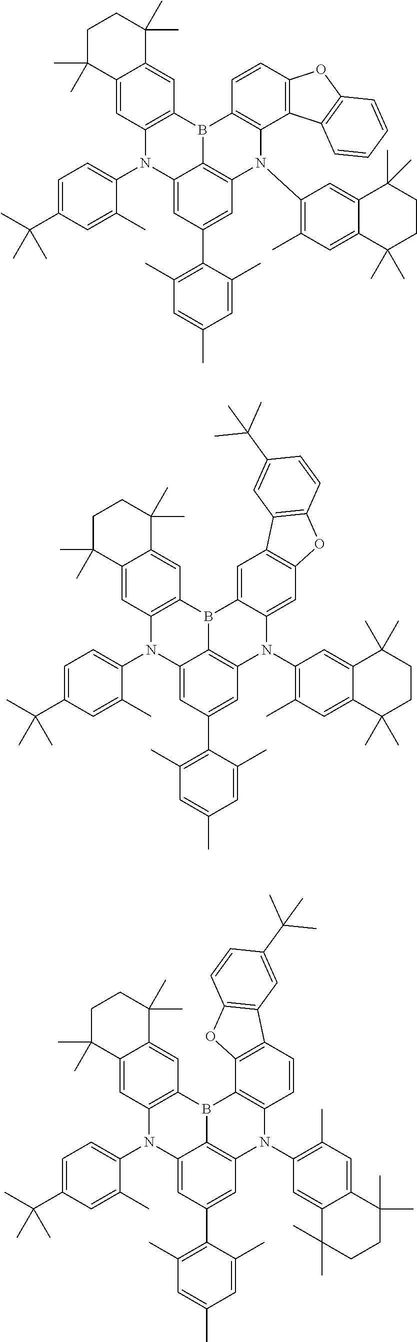 [SMILES: Cc1cc(C)c(-c2cc3c4c(c2)N(c2cc5c(cc2C)C(C)(C)CCC5(C)C)c2c(ccc5oc6ccccc6c25)B4c2cc4c(cc2N3c2ccc(C(C)(C)C)cc2C)C(C)(C)CCC4(C)C)c(C)c1 ; Cc1cc(C)c(-c2cc3c4c(c2)N(c2cc5c(cc2C)C(C)(C)CCC5(C)C)c2cc5oc6ccc(C(C)(C)C)cc6c5cc2B4c2cc4c(cc2N3c2ccc(C(C)(C)C)cc2C)C(C)(C)CCC4(C)C)c(C)c1 ; Cc1cc(C)c(-c2cc3c4c(c2)N(c2cc5c(cc2C)C(C)(C)CCC5(C)C)c2ccc5c(oc6ccc(C(C)(C)C)cc65)c2B4c2cc4c(cc2N3c2ccc(C(C)(C)C)cc2C)C(C)(C)CCC4(C)C)c(C)c1]

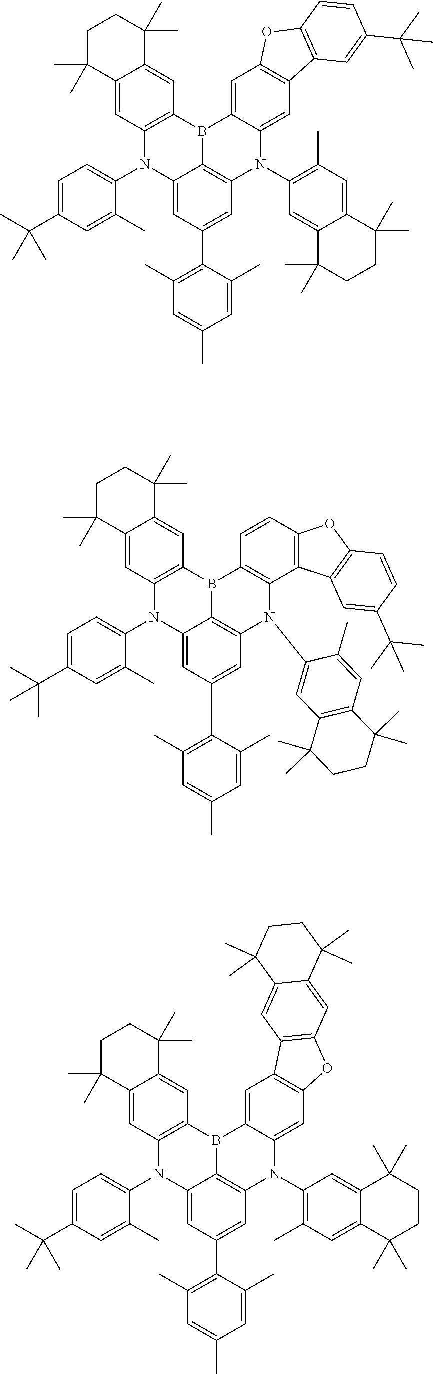

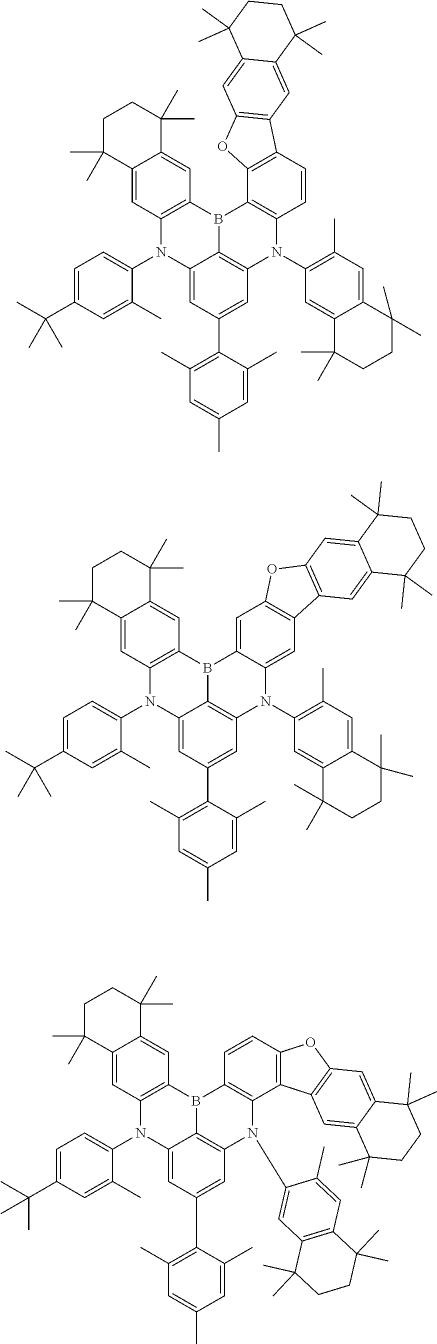

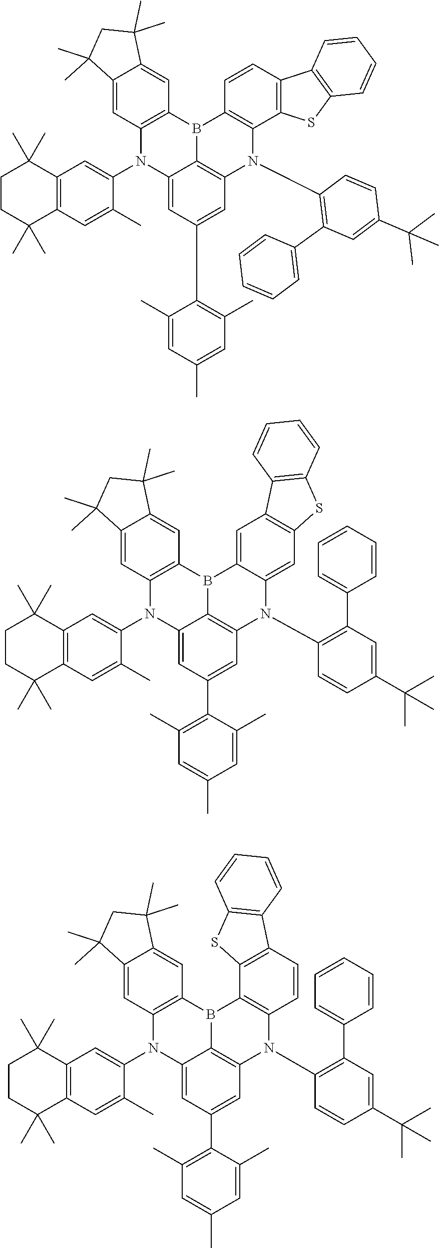 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2cc3c(cc2C)C(C)(C)CCC3(C)C)C(C)(C)CC4(C)C)c(C)c1]

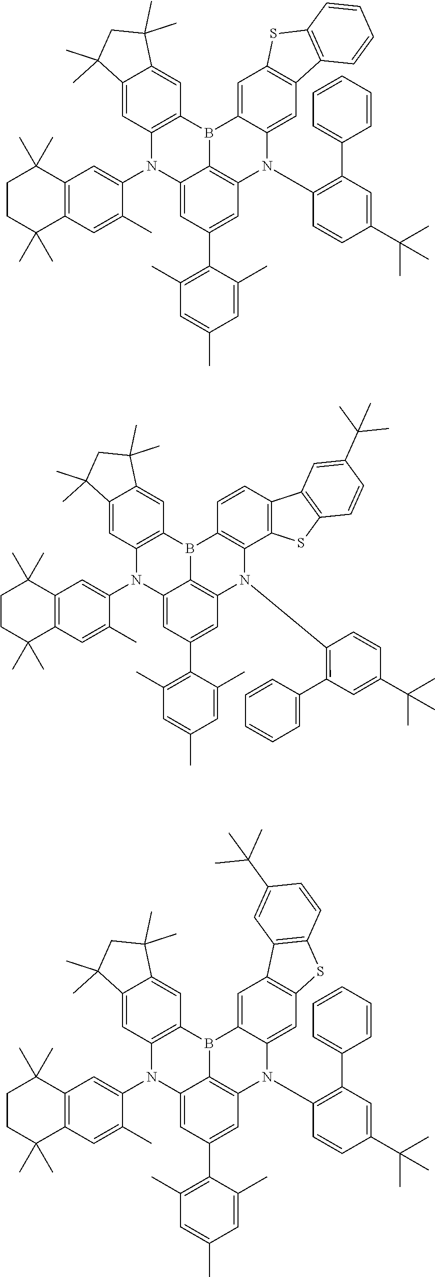 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1]

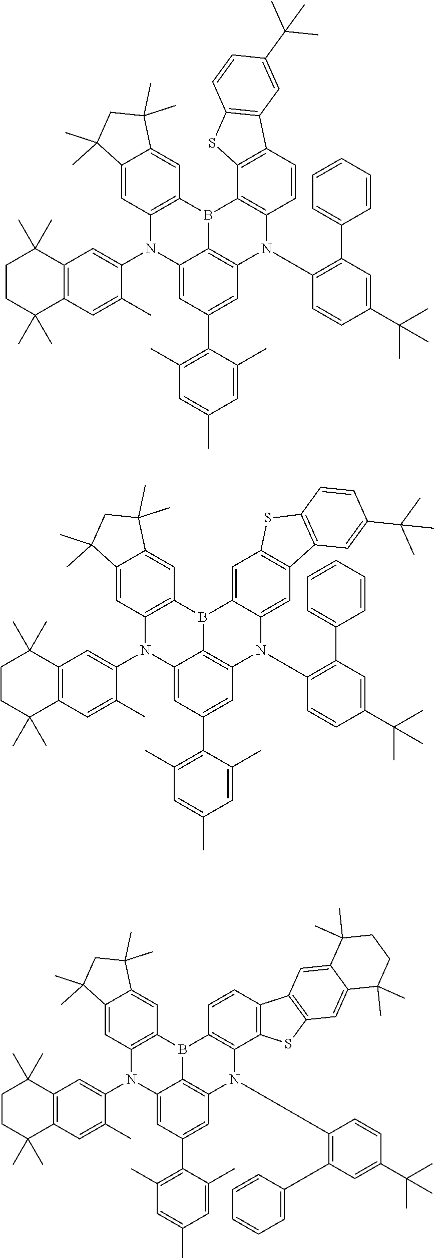 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

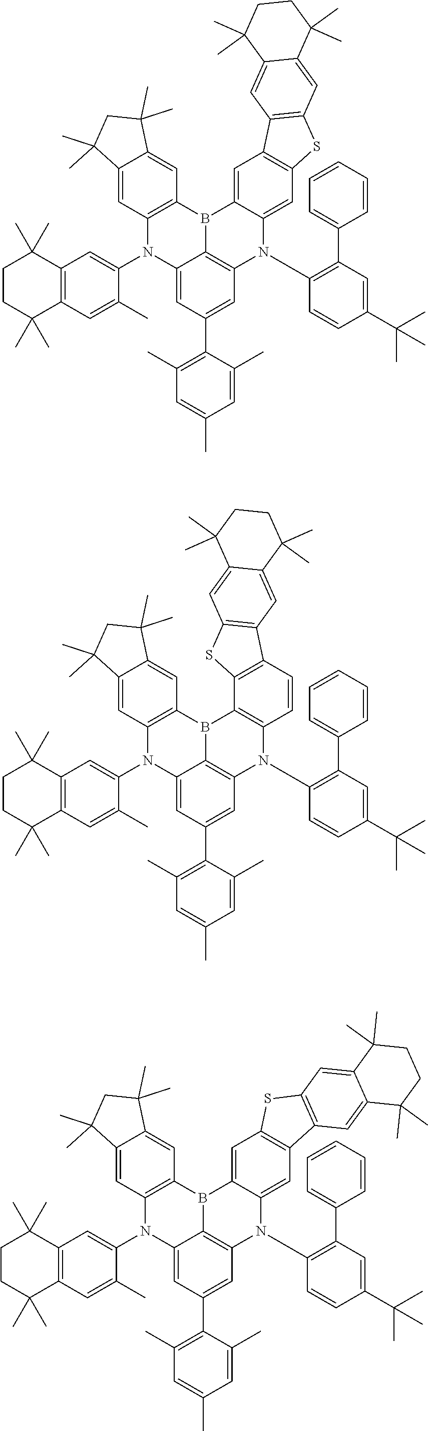 [SMILES: Cc1cc(C)c(-c2cc3c4c(c2)N(c2ccc(C(C)(C)C)cc2-c2ccccc2)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1 ; Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1]

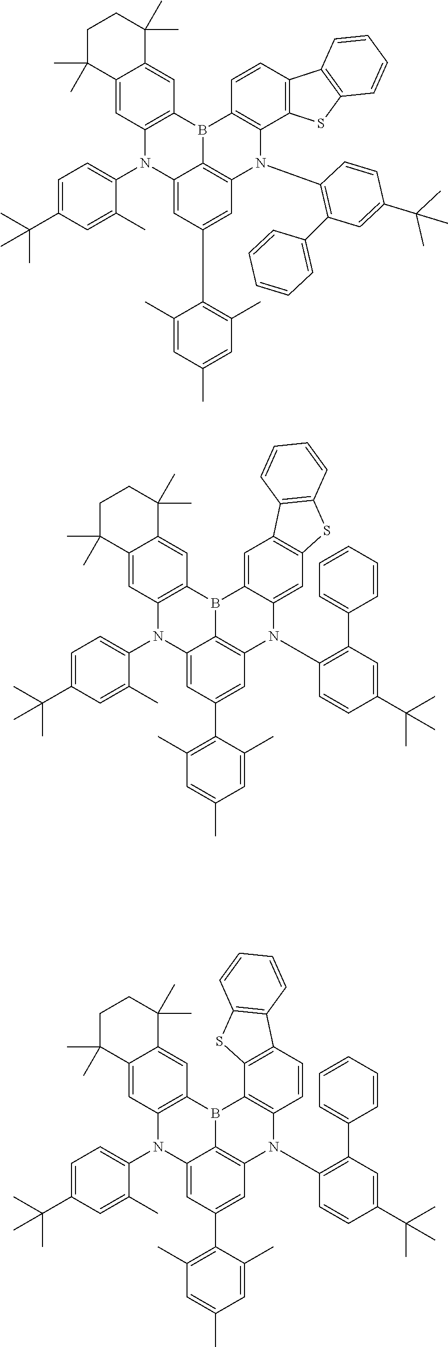

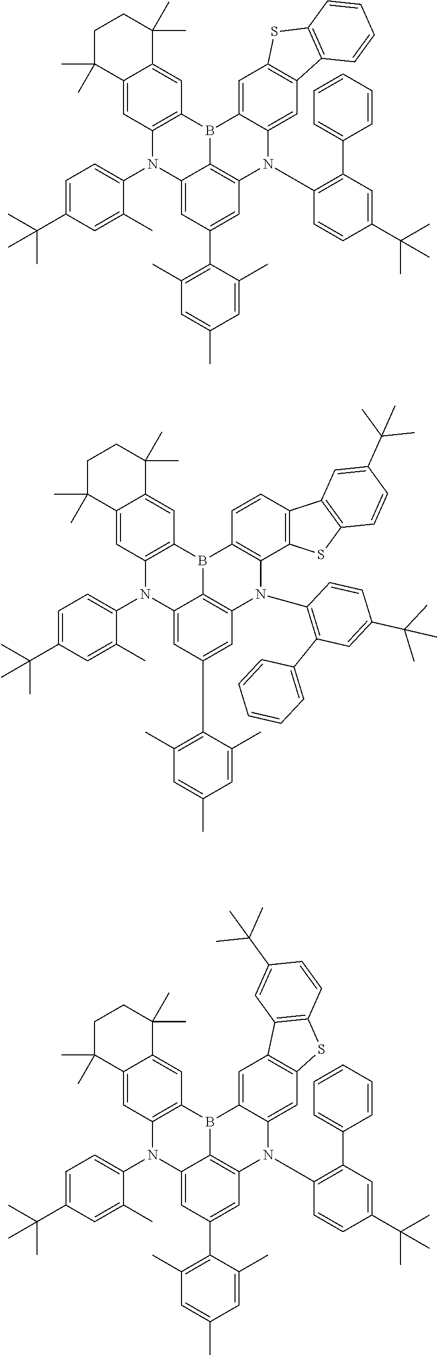

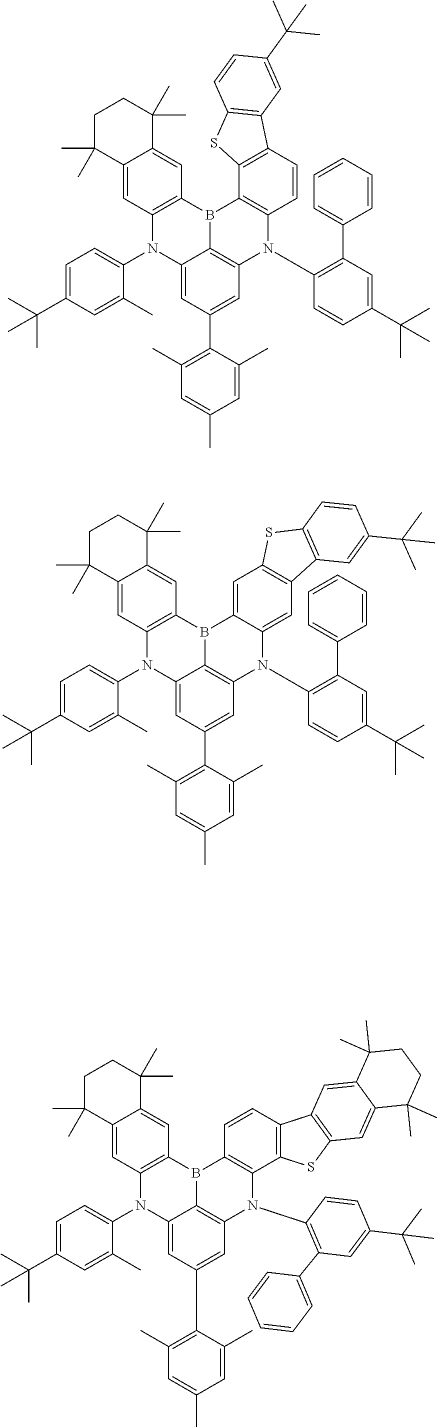

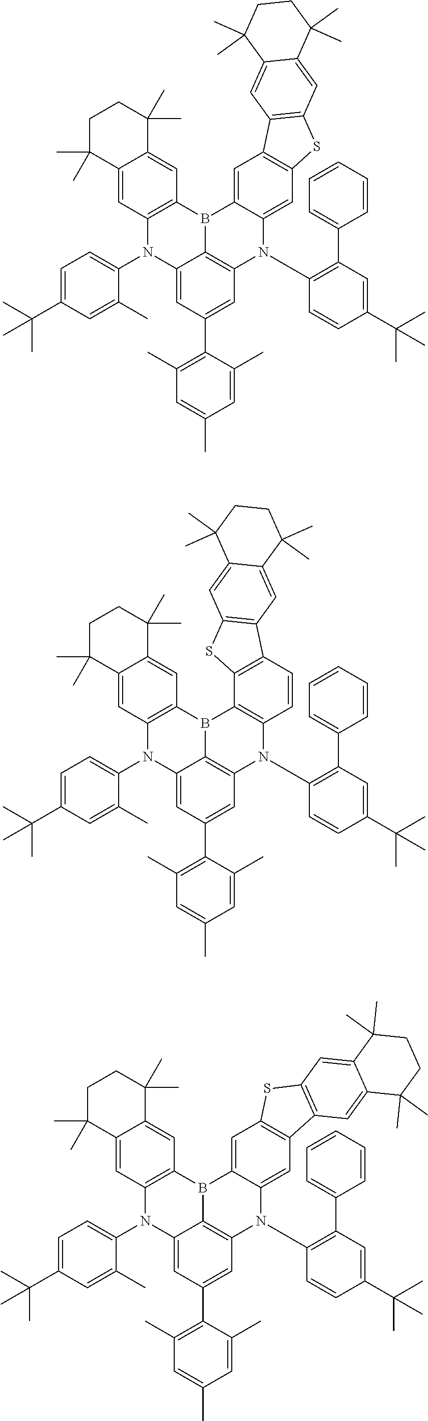

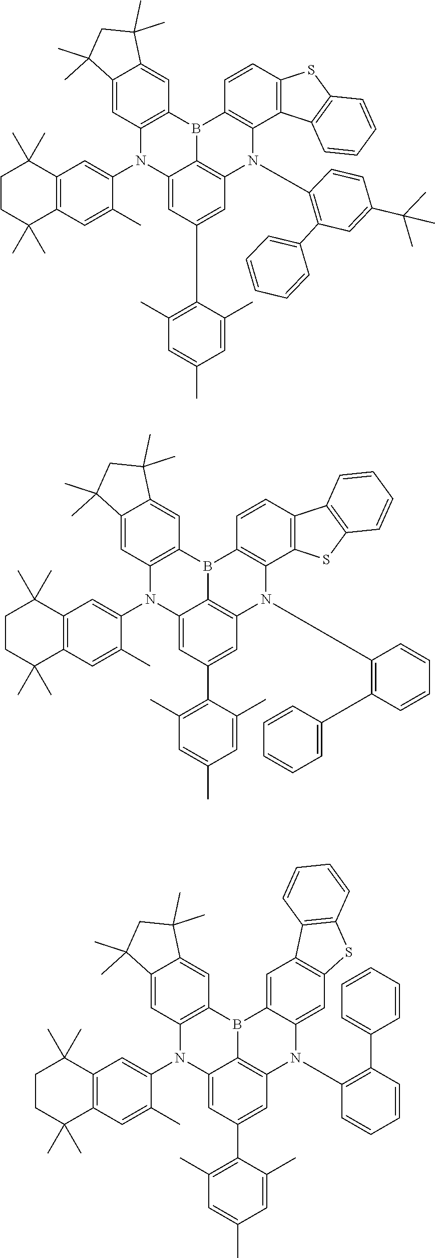 [SMILES: Cc1cc(C)c(-c2cc3c4c(c2)N(c2ccc(C(C)(C)C)cc2-c2ccccc2)c2c(ccc5sc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2c(ccc5c2sc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5sc6ccccc6c5cc2B4c2cc4c(cc2N3c2cc3c(cc2C)C(C)(C)CCC3(C)C)C(C)(C)CC4(C)C)c(C)c1]

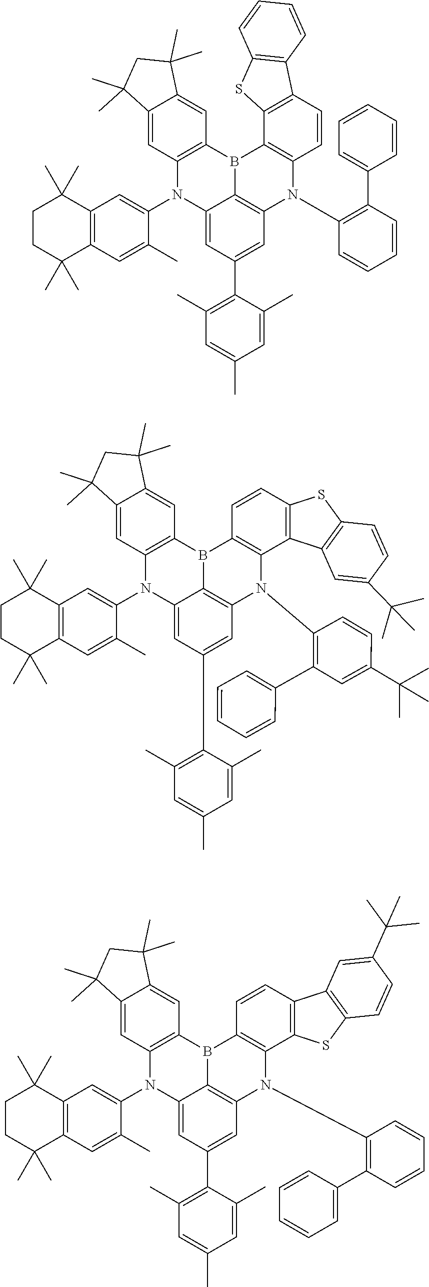 [SMILES: Cc1cc(C)c(-c2cc3c4c(c2)N(c2ccccc2-c2ccccc2)c2ccc5c(sc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1]

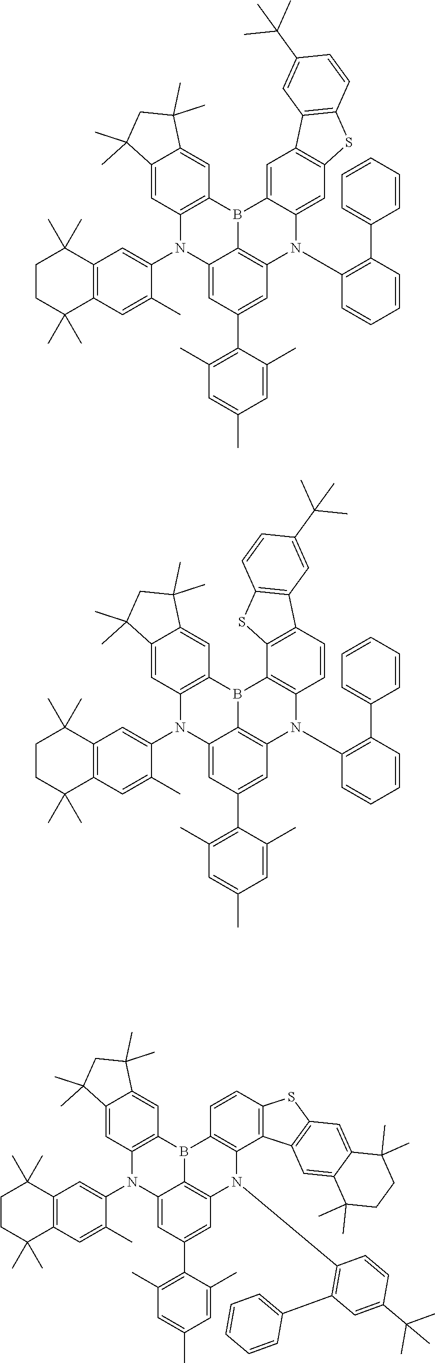 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1]

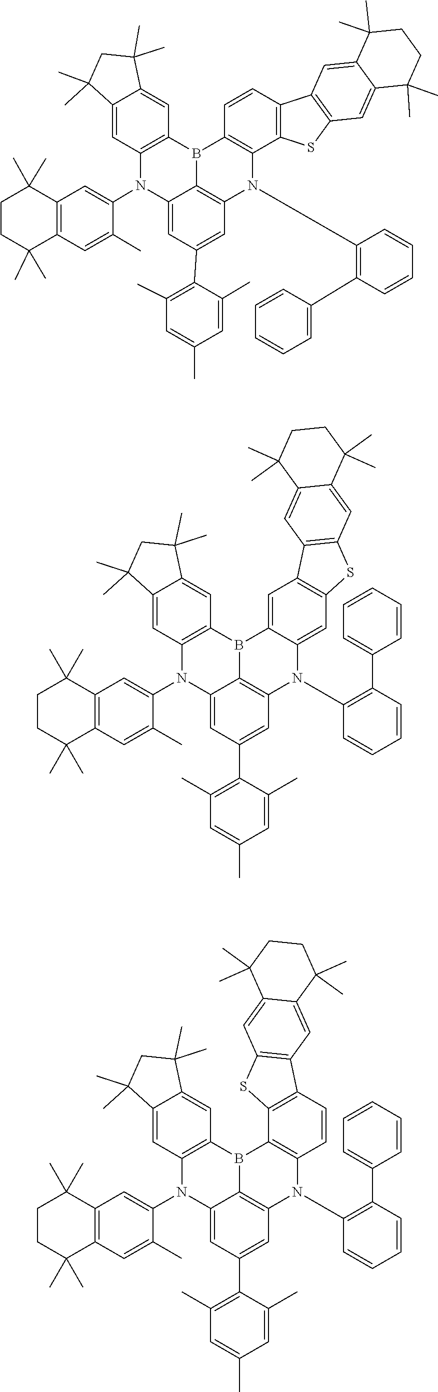 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

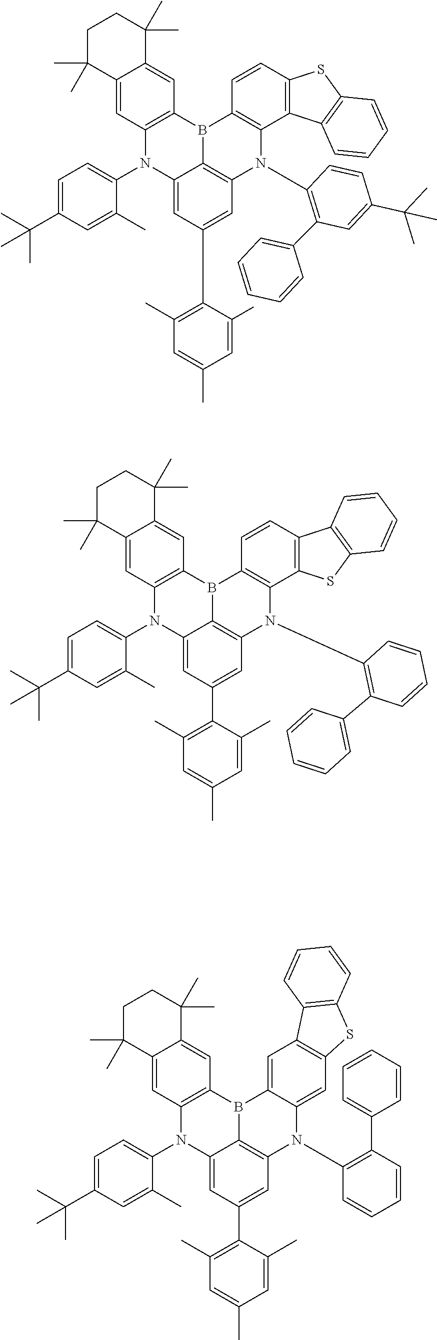

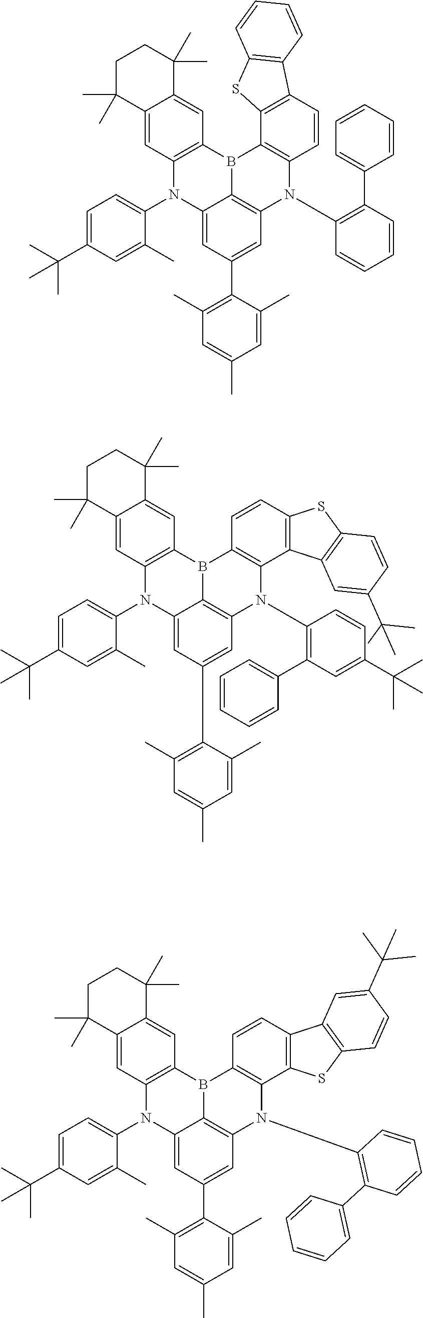

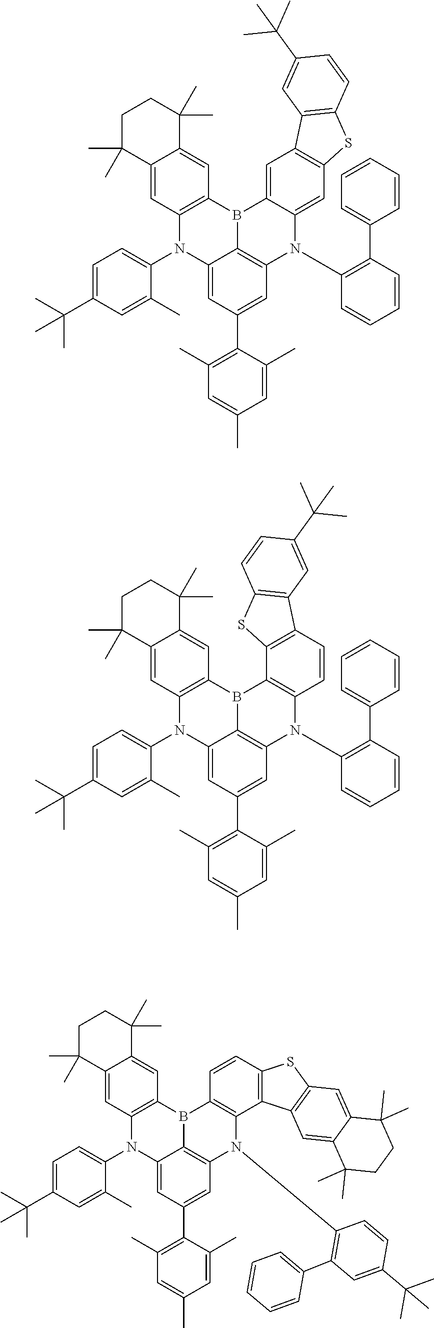 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc(C(C)(C)C)cc2C)C(C)(C)CCC4(C)C)c(C)c1]

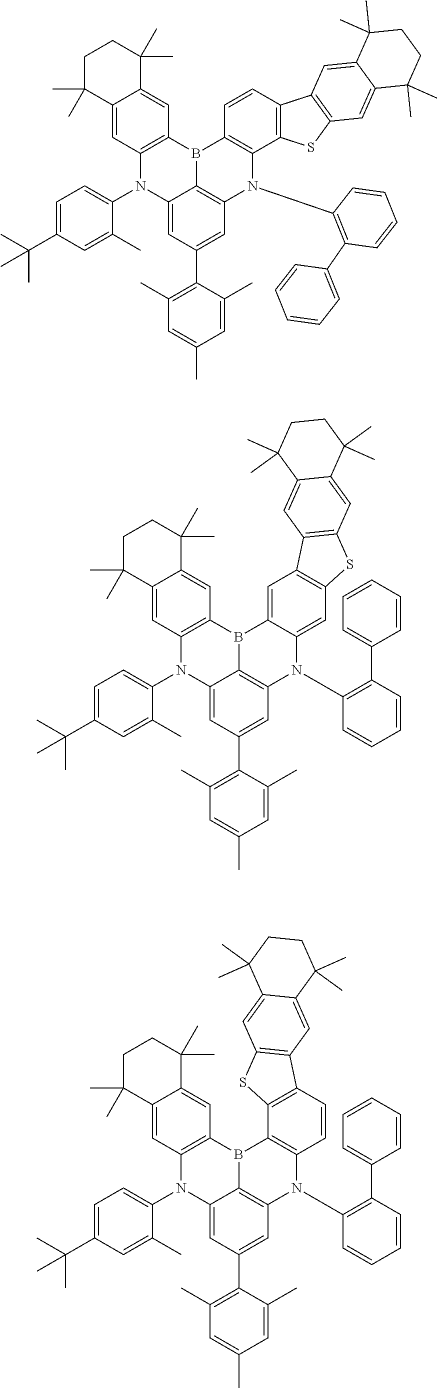

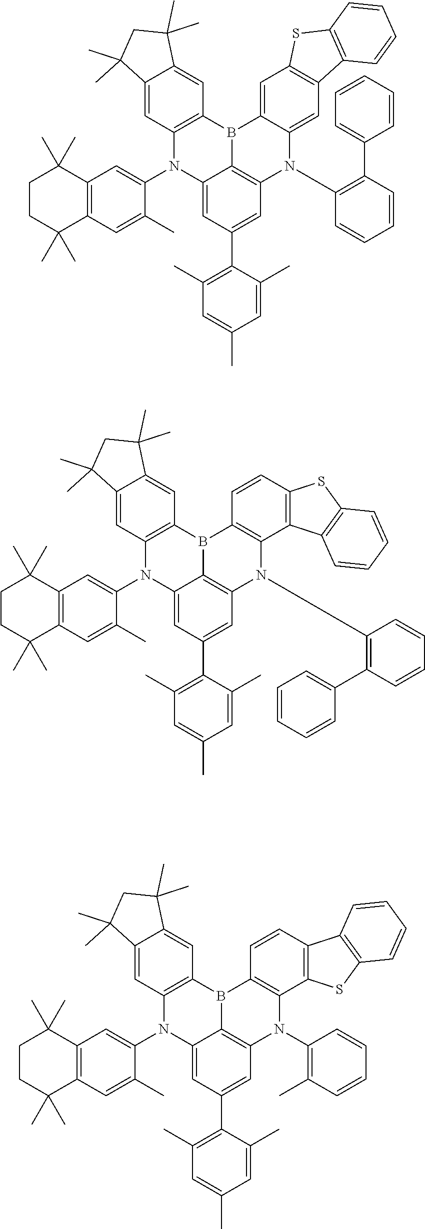 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2sc2ccccc25)B4c2cc4c(cc2N3c2cc3c(cc2C)C(C)(C)CCC3(C)C)C(C)(C)CC4(C)C)c(C)c1]

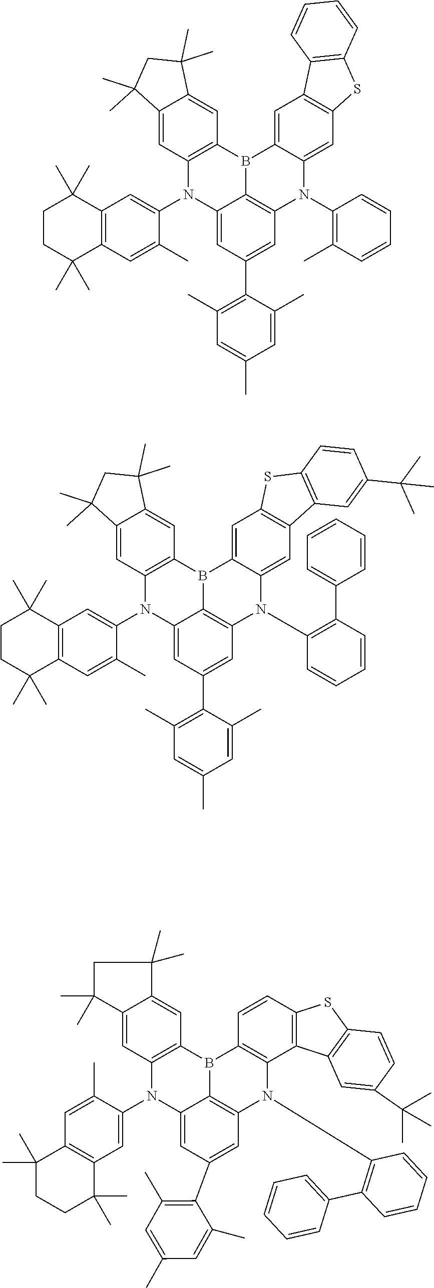

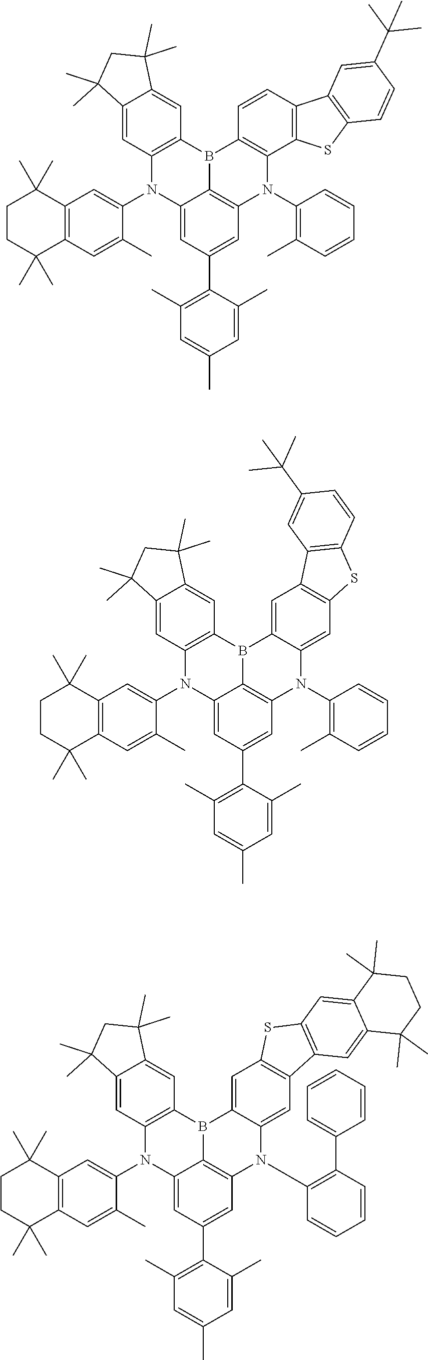 [SMILES: Cc1cc(C)c(-c2cc3c4c(c2)N(c2ccccc2C)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1]

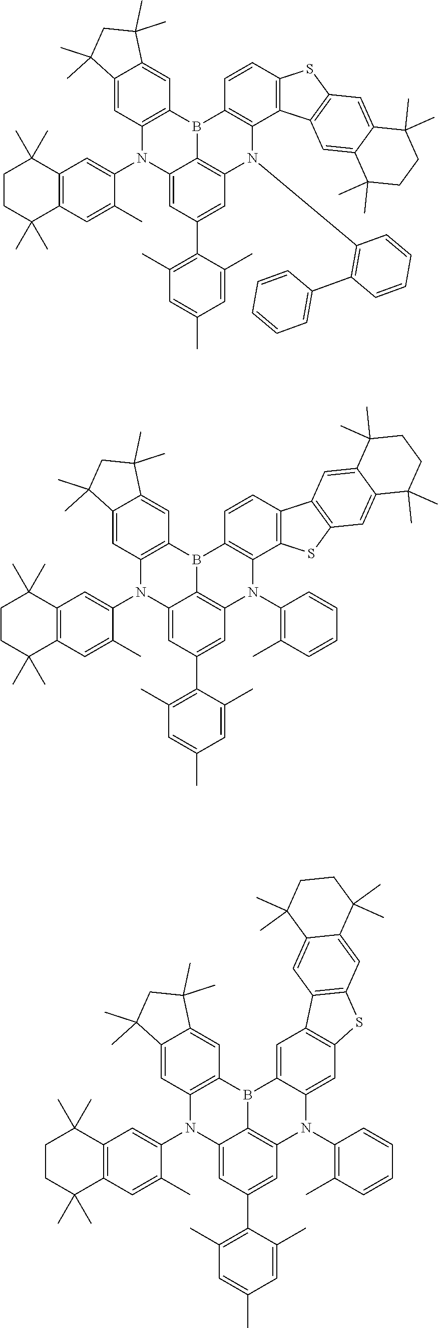 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

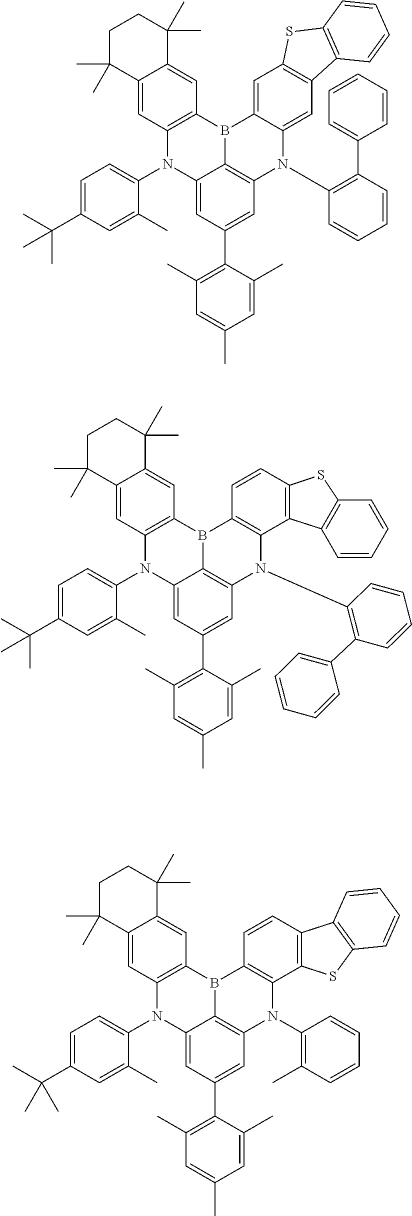 [SMILES: Cc1cc(C)c(-c2cc3c4c(c2)N(c2ccccc2-c2ccccc2)c2cc5c(cc2B4c2cc4c(cc2N3c2ccc(C(C)(C)C)cc2C)C(C)(C)CCC4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2c(ccc5c2sc2ccccc25)B4c2cc4c(cc2N3c2ccc(C(C)(C)C)cc2C)C(C)(C)CCC4(C)C)c(C)c1]

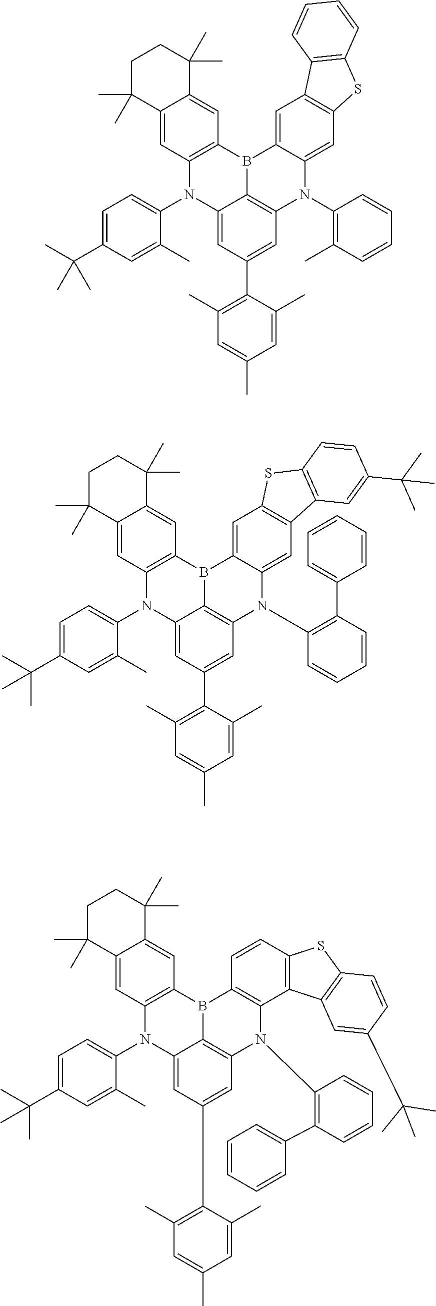

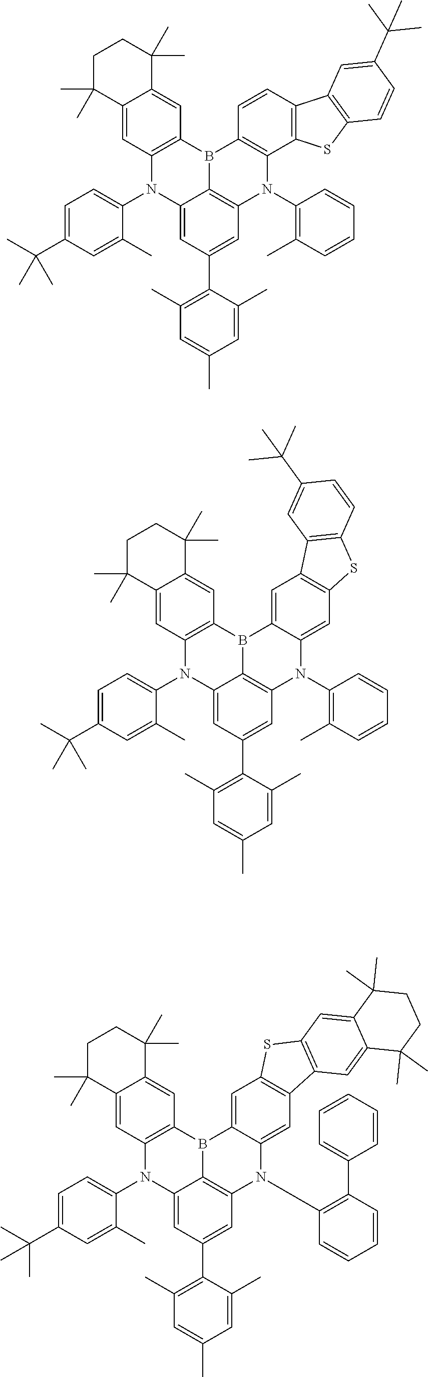

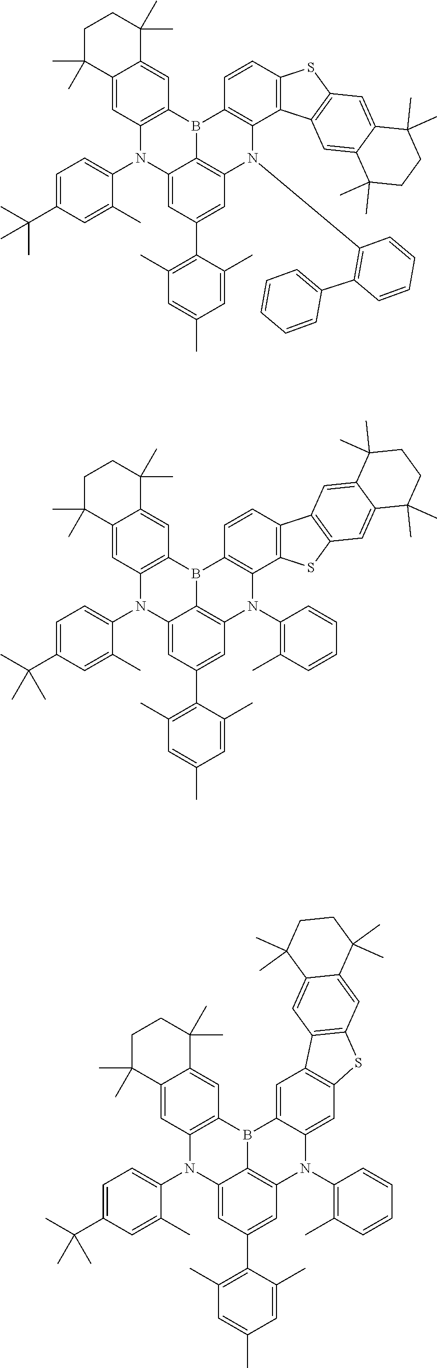

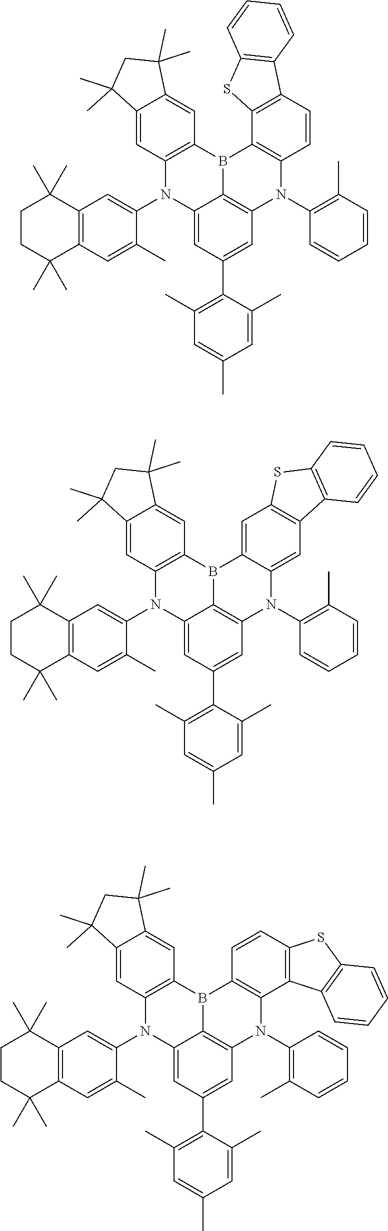 [SMILES: Cc1cc(C)c(-c2cc3c4c(c2)N(c2ccccc2C)c2ccc5c(sc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2cc3c(cc2C)C(C)(C)CCC3(C)C)C(C)(C)CC4(C)C)c(C)c1]

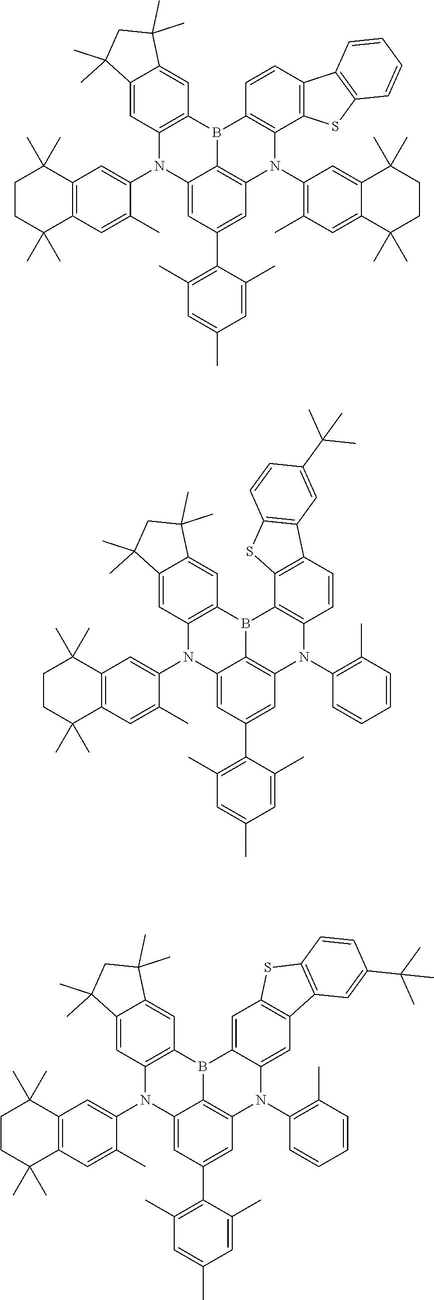 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)sc2ccc(C(C)(C)C)cc25)c(C)c1]

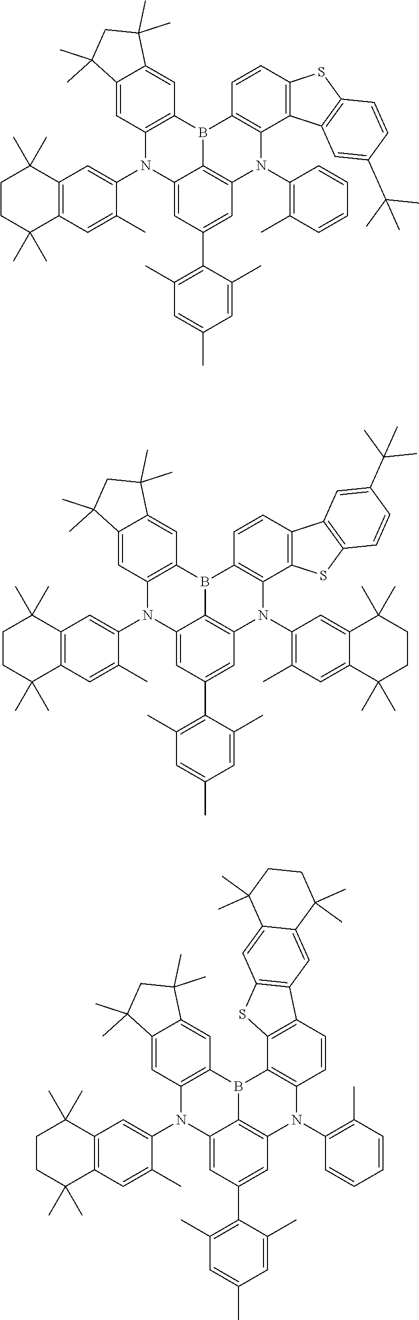 [SMILES: Cc1cc(C)c(-c2cc3c4c(c2)N(c2ccccc2C)c2c(ccc5sc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

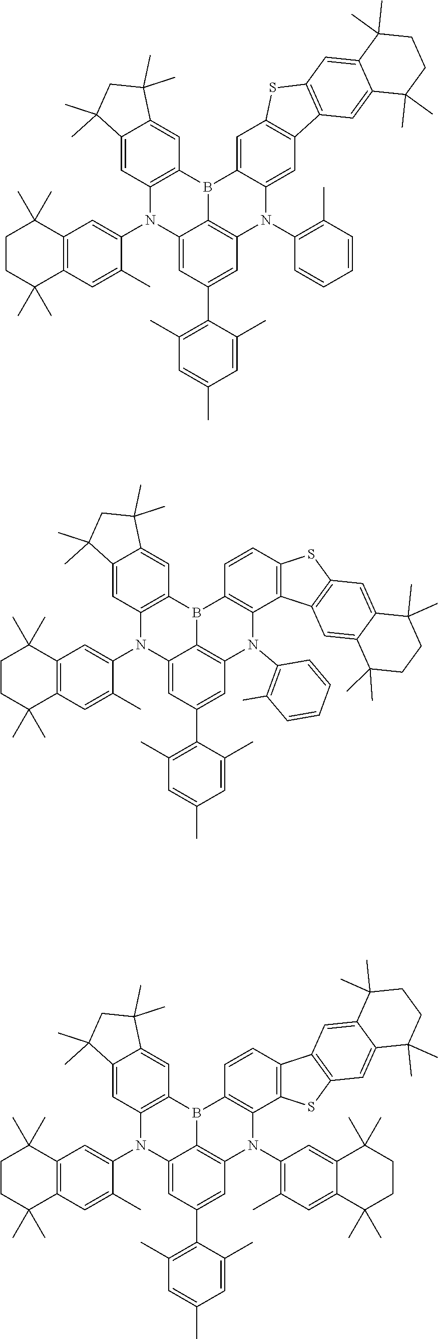 [SMILES: Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1 ; Cc1cc(C)c(-c2cc3c4c(c2)N(c2ccccc2C)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

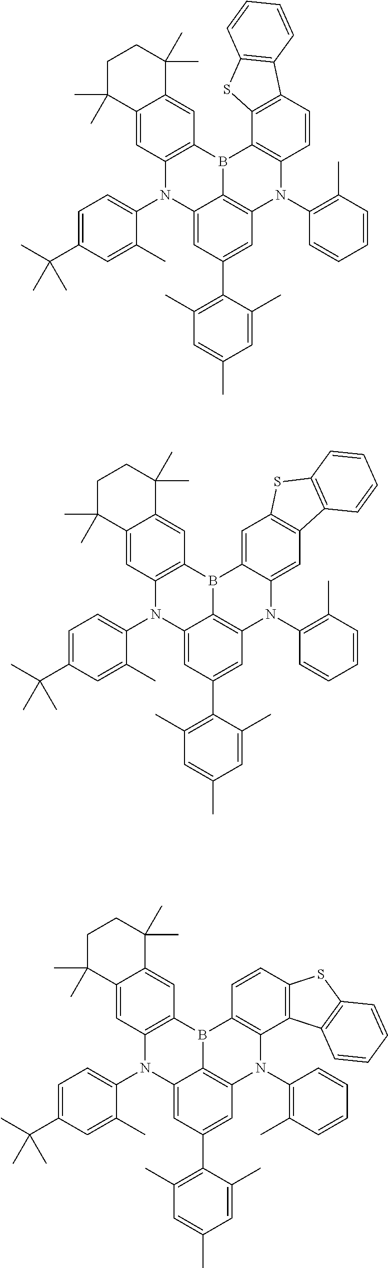 [SMILES: Cc1cc(C)c(-c2cc3c4c(c2)N(c2ccccc2C)c2ccc5c(sc6ccccc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2ccc(C(C)(C)C)cc2C)C(C)(C)CCC4(C)C)c(C)c1]

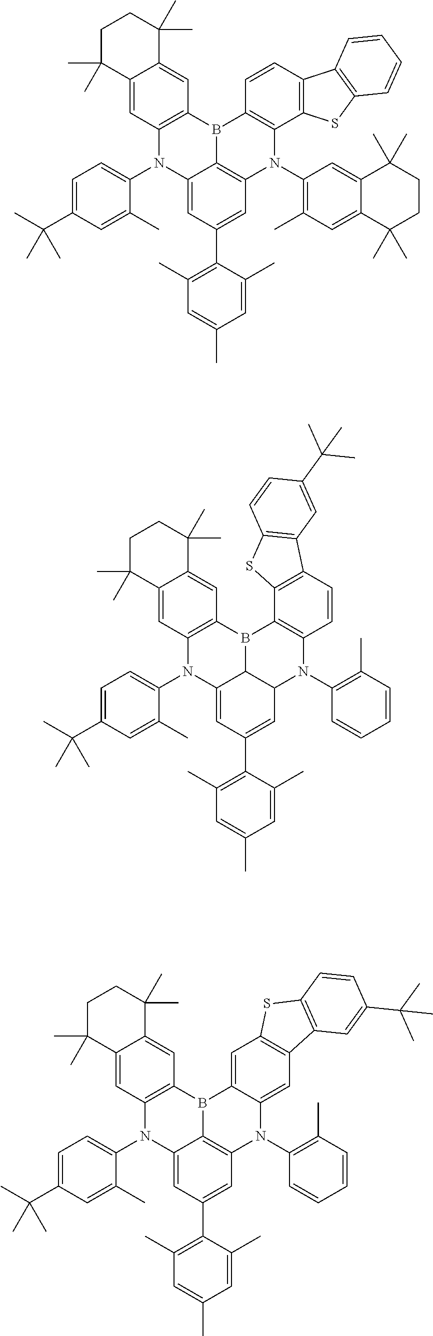 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2ccc(C(C)(C)C)cc2C)C(C)(C)CCC4(C)C)c(C)c1 ; Cc1cc(C)c(C2=CC3C4B(c5cc6c(cc5N(c5ccc(C(C)(C)C)cc5C)C4=C2)C(C)(C)CCC6(C)C)c2c(ccc4c2sc2ccc(C(C)(C)C)cc24)N3c2ccccc2C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)sc2ccc(C(C)(C)C)cc25)c(C)c1]

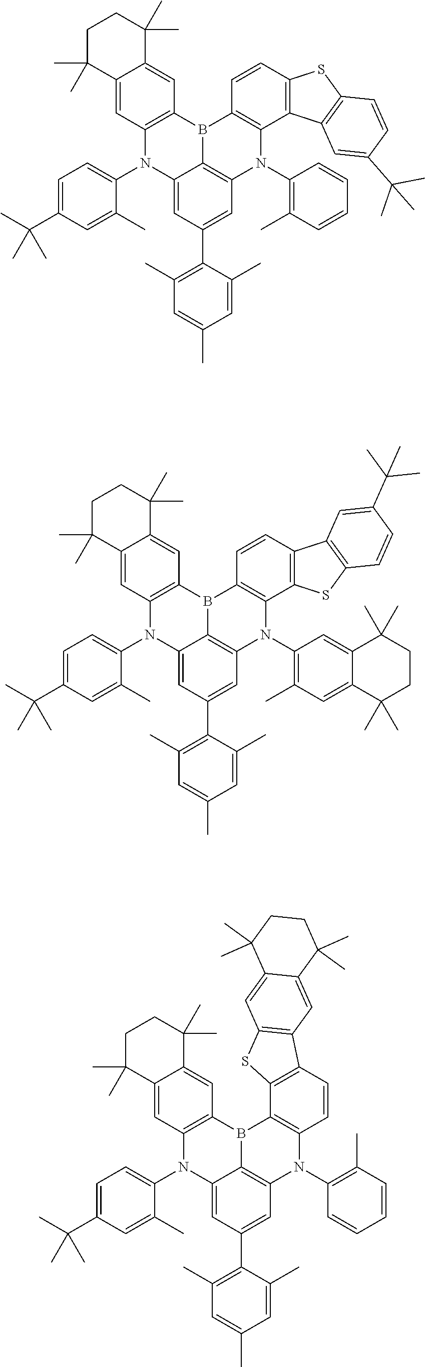

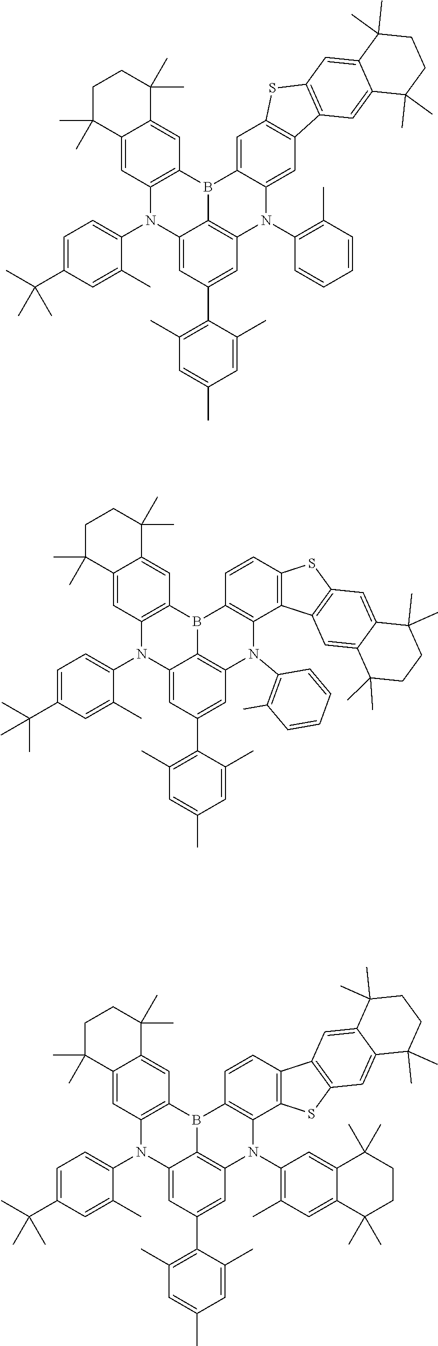

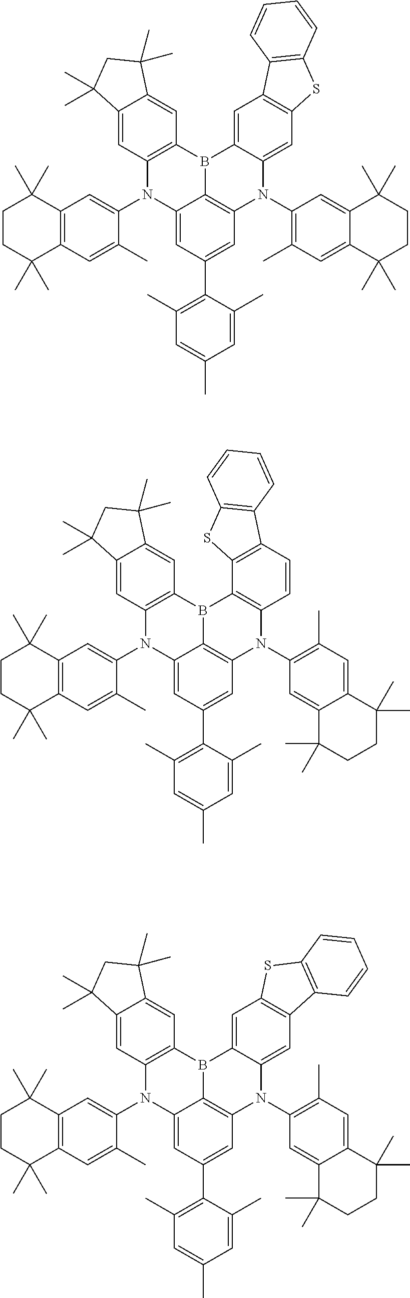 [SMILES: Cc1cc(C)c(-c2cc3c4c(c2)N(c2cc5c(cc2C)C(C)(C)CCC5(C)C)c2cc5sc6ccccc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2ccc5c(sc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)sc2ccccc25)c(C)c1]

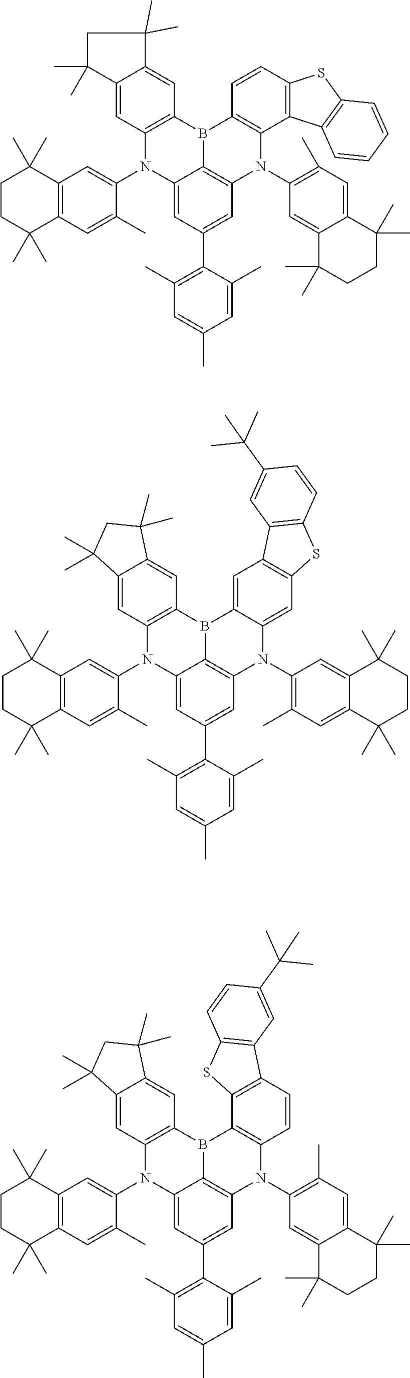 [SMILES: Cc1cc(C)c(-c2cc3c4c(c2)N(c2cc5c(cc2C)C(C)(C)CCC5(C)C)c2c(ccc5sc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1]

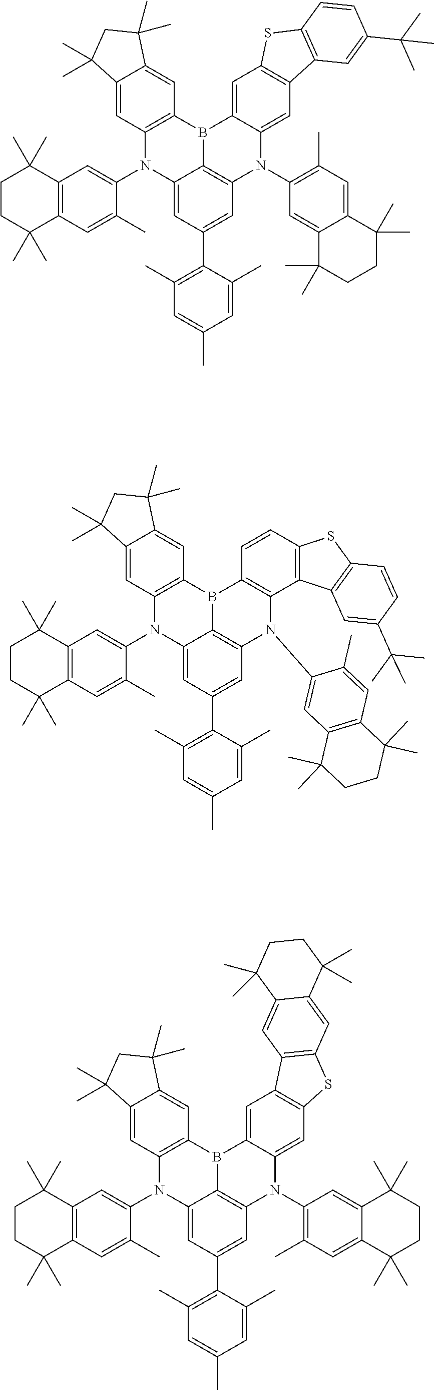 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

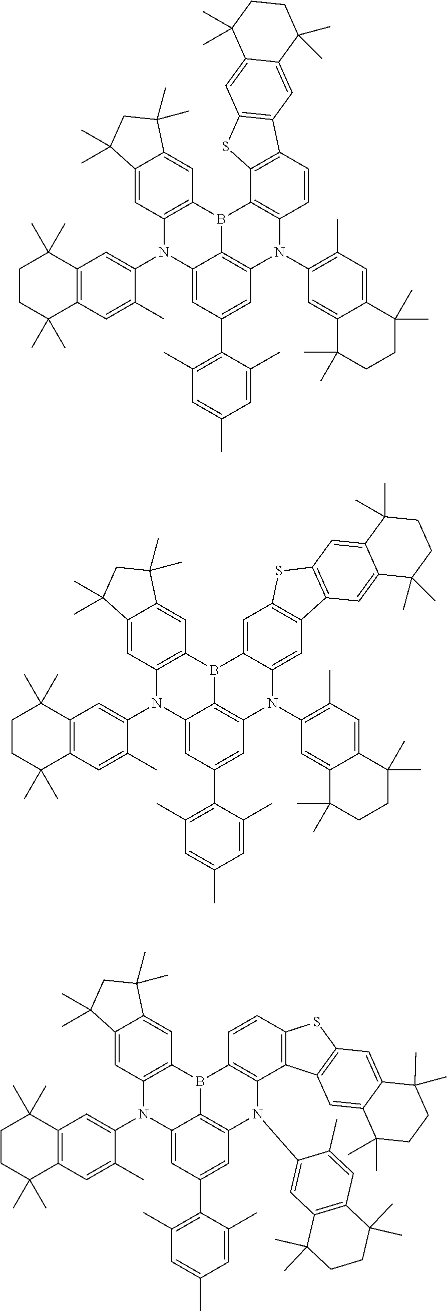 [SMILES: Cc1cc(C)c(-c2cc3c4c(c2)N(c2cc5c(cc2C)C(C)(C)CCC5(C)C)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1]

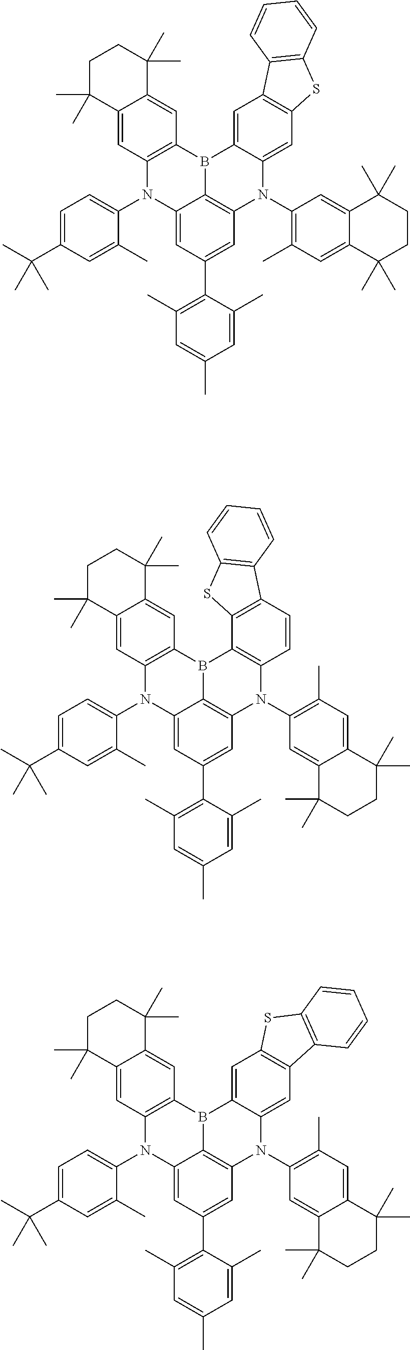

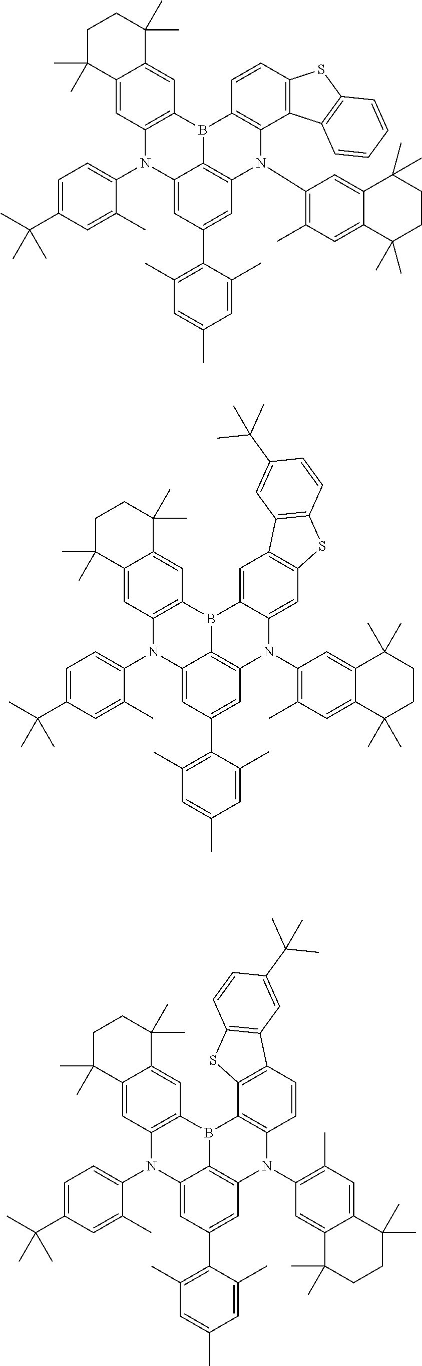

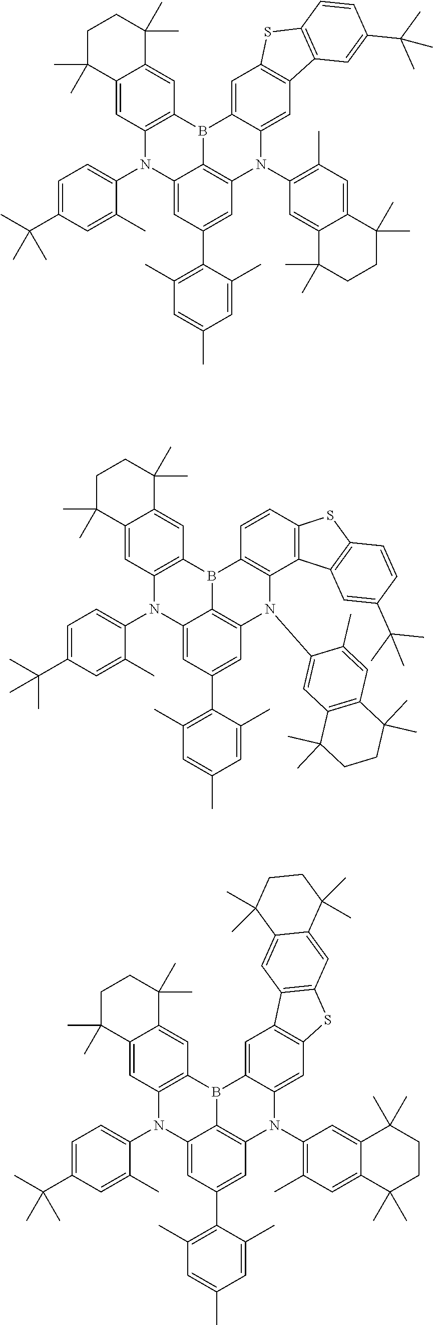

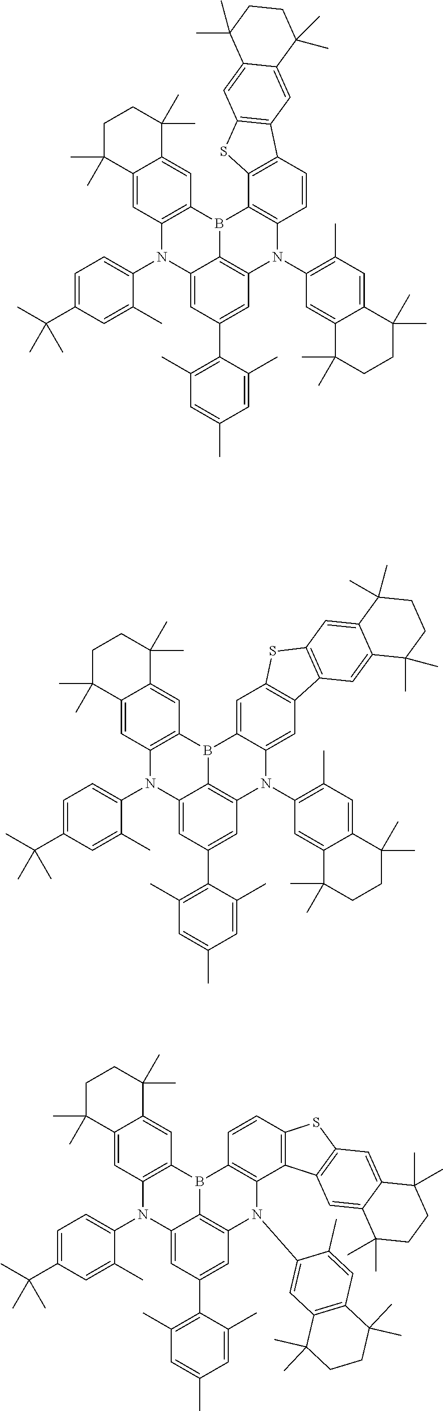

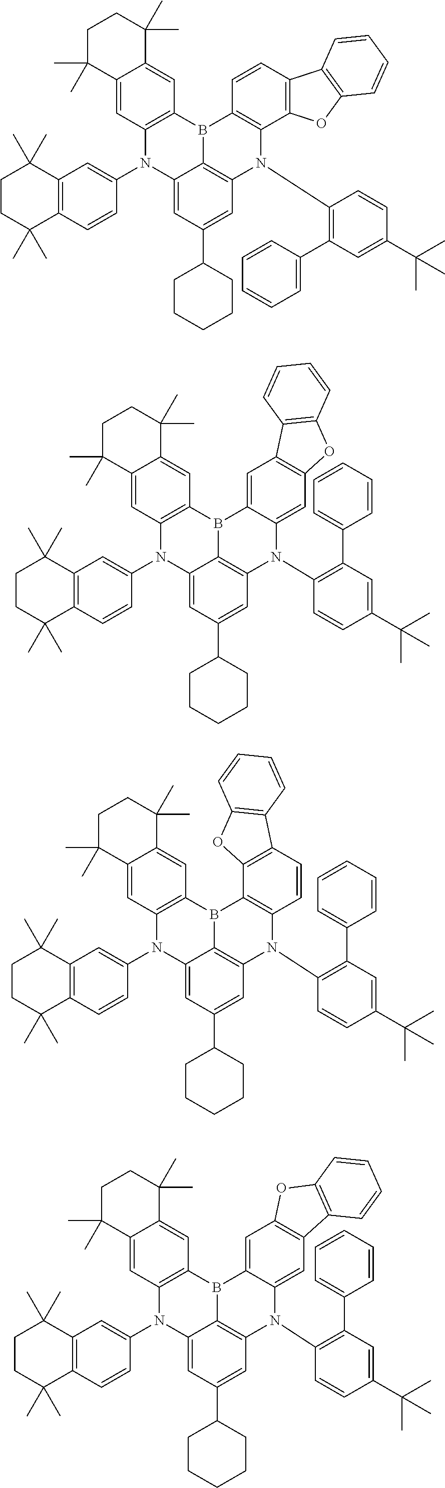

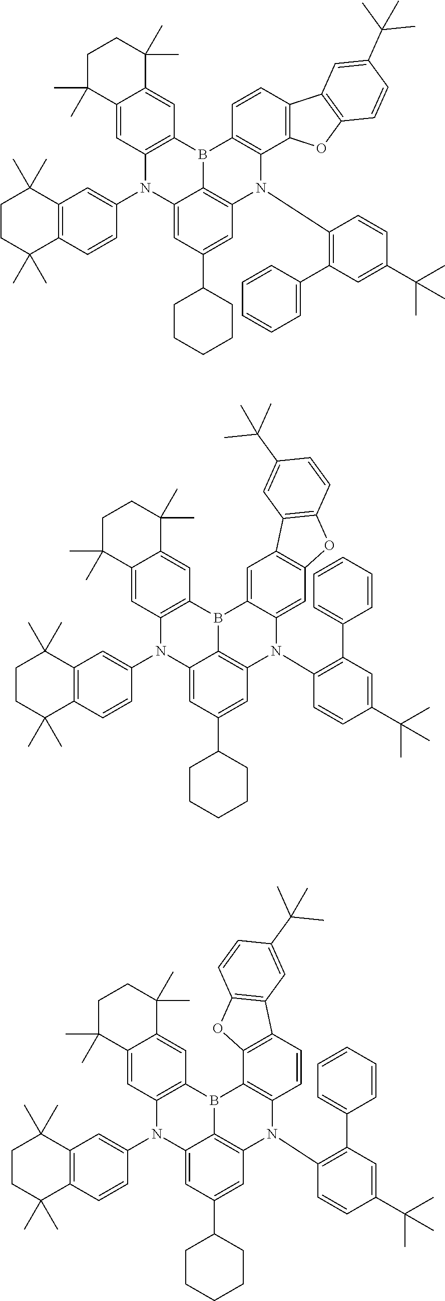 [SMILES: CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c32)c(-c2ccccc2)c1 ; CC(C)(C)c1ccc(N2c3cc4oc5ccc(C(C)(C)C)cc5c4cc3B3c4cc5c(cc4N(c4ccc6c(c4)C(C)(C)CCC6(C)C)c4cc(C6CCCCC6)cc2c43)C(C)(C)CCC5(C)C)c(-c2ccccc2)c1 ; CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3c2ccc2c3oc3ccc(C(C)(C)C)cc32)c(-c2ccccc2)c1]

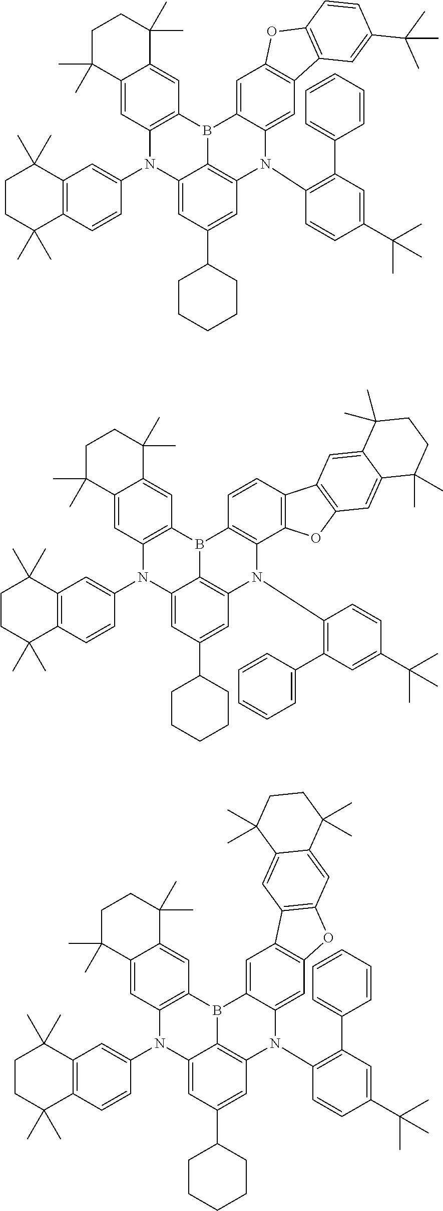 [SMILES: CC(C)(C)c1ccc(N2c3cc4c(cc3B3c5cc6c(cc5N(c5ccc7c(c5)C(C)(C)CCC7(C)C)c5cc(C7CCCCC7)cc2c53)C(C)(C)CCC6(C)C)oc2ccc(C(C)(C)C)cc24)c(-c2ccccc2)c1 ; CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c32)c(-c2ccccc2)c1 ; CC(C)(C)c1ccc(N2c3cc4oc5cc6c(cc5c4cc3B3c4cc5c(cc4N(c4ccc7c(c4)C(C)(C)CCC7(C)C)c4cc(C7CCCCC7)cc2c43)C(C)(C)CCC5(C)C)C(C)(C)CCC6(C)C)c(-c2ccccc2)c1]

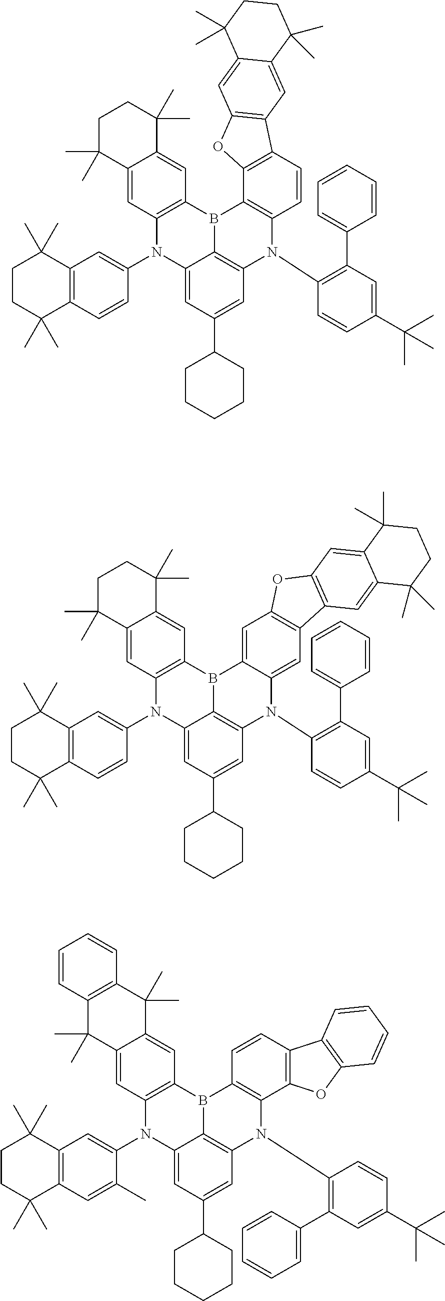 [SMILES: CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3c2ccc2c3oc3cc4c(cc32)C(C)(C)CCC4(C)C)c(-c2ccccc2)c1 ; CC(C)(C)c1ccc(N2c3cc4c(cc3B3c5cc6c(cc5N(c5ccc7c(c5)C(C)(C)CCC7(C)C)c5cc(C7CCCCC7)cc2c53)C(C)(C)CCC6(C)C)oc2cc3c(cc24)C(C)(C)CCC3(C)C)c(-c2ccccc2)c1 ; Cc1cc2c(cc1N1c3cc4c(cc3B3c5ccc6c(oc7ccccc76)c5N(c5ccc(C(C)(C)C)cc5-c5ccccc5)c5cc(C6CCCCC6)cc1c53)C(C)(C)c1ccccc1C4(C)C)C(C)(C)CCC2(C)C]

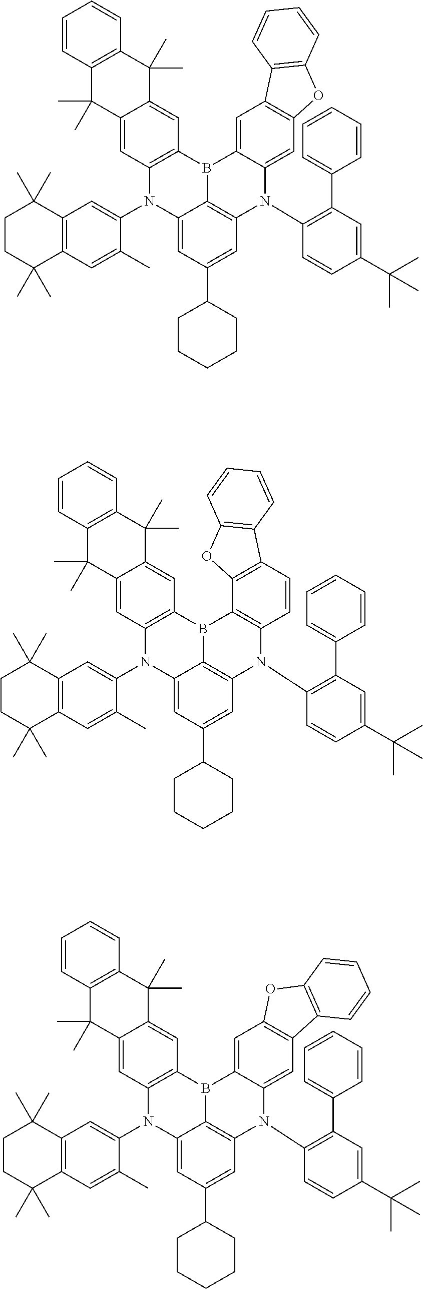 [SMILES: Cc1cc2c(cc1N1c3cc4c(cc3B3c5cc6c(cc5N(c5ccc(C(C)(C)C)cc5-c5ccccc5)c5cc(C7CCCCC7)cc1c53)oc1ccccc16)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccc(C(C)(C)C)cc1-c1ccccc1)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5ccc(C(C)(C)C)cc5-c5ccccc5)c5cc(C6CCCCC6)cc1c53)C(C)(C)c1ccccc1C4(C)C)C(C)(C)CCC2(C)C]

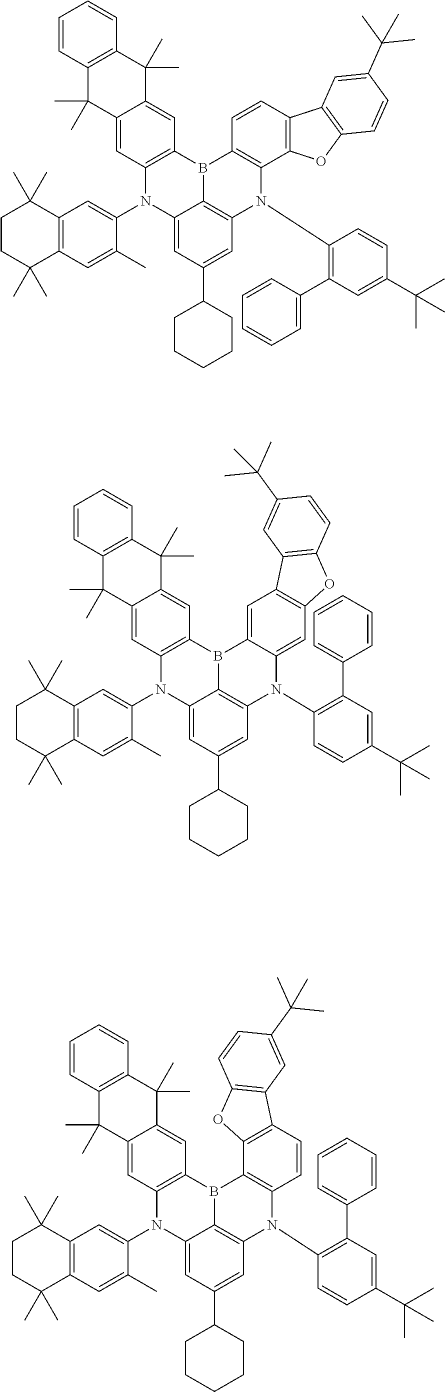 [SMILES: Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccc(C(C)(C)C)cc1-c1ccccc1)c1ccc5c(oc6ccc(C(C)(C)C)cc65)c13)C(C)(C)c1ccccc1C4(C)C)C(C)(C)CCC2(C)C]

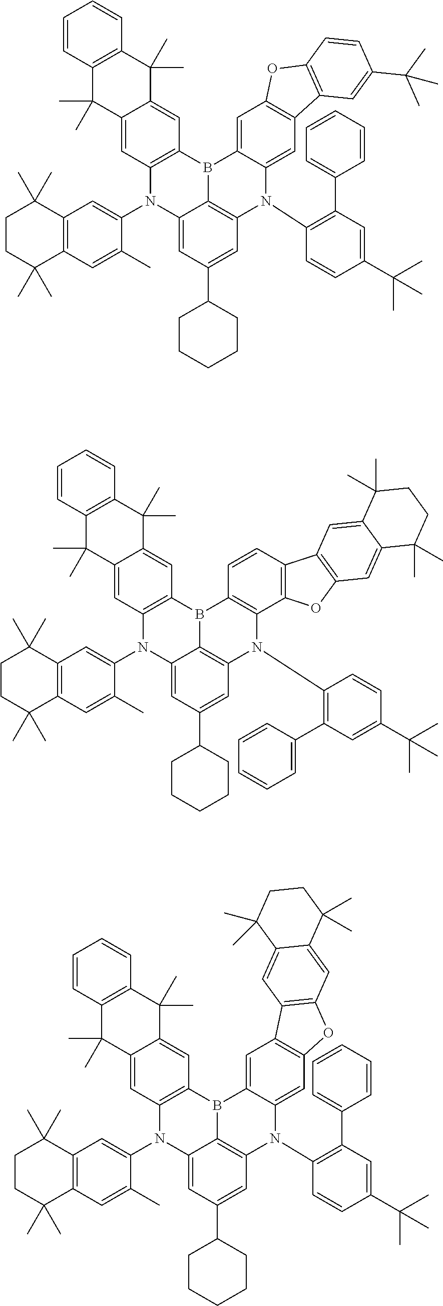 [SMILES: Cc1cc2c(cc1N1c3cc4c(cc3B3c5cc6oc7ccc(C(C)(C)C)cc7c6cc5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)oc1cc3c(cc16)C(C)(C)CCC3(C)C)C(C)(C)c1ccccc1C4(C)C)C(C)(C)CCC2(C)C]

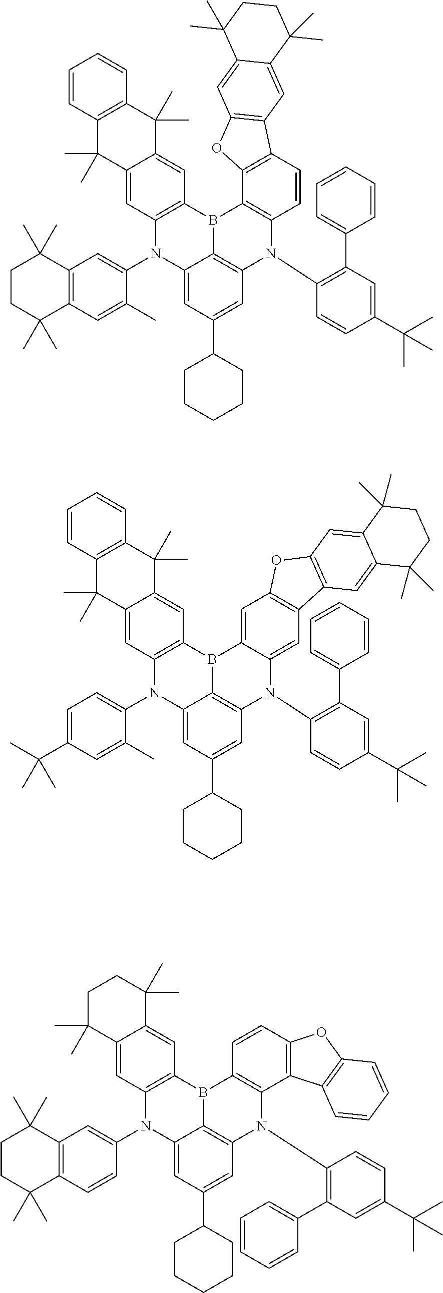

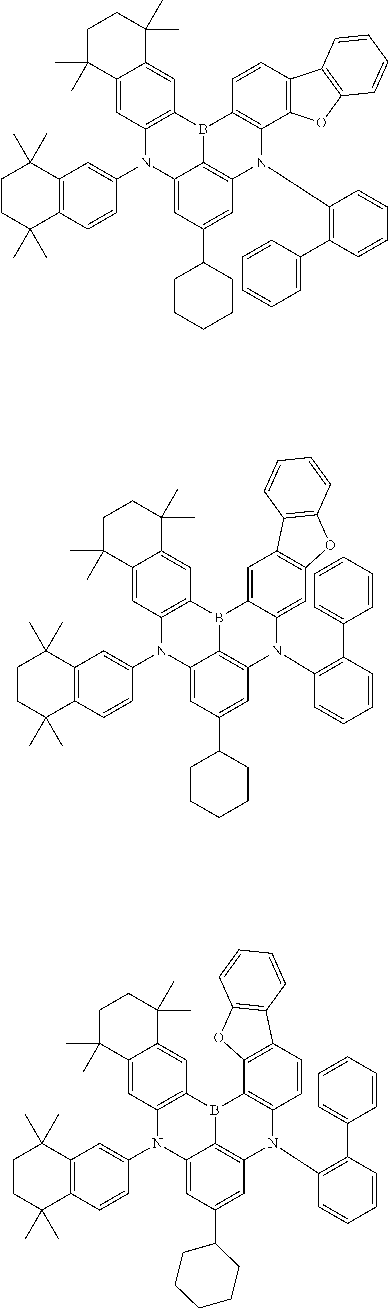 [SMILES: CC1(C)CCC(C)(C)c2cc(N3c4cc5c(cc4B4c6ccc7c(oc8ccccc87)c6N(c6ccccc6-c6ccccc6)c6cc(C7CCCCC7)cc3c64)C(C)(C)CCC5(C)C)ccc21 ; CC1(C)CCC(C)(C)c2cc(N3c4cc5c(cc4B4c6cc7c(cc6N(c6ccccc6-c6ccccc6)c6cc(C8CCCCC8)cc3c64)oc3ccccc37)C(C)(C)CCC5(C)C)ccc21 ; CC1(C)CCC(C)(C)c2cc(N3c4cc5c(cc4B4c6c3cc(C3CCCCC3)cc6N(c3ccccc3-c3ccccc3)c3ccc6c(oc7ccccc76)c34)C(C)(C)CCC5(C)C)ccc21]

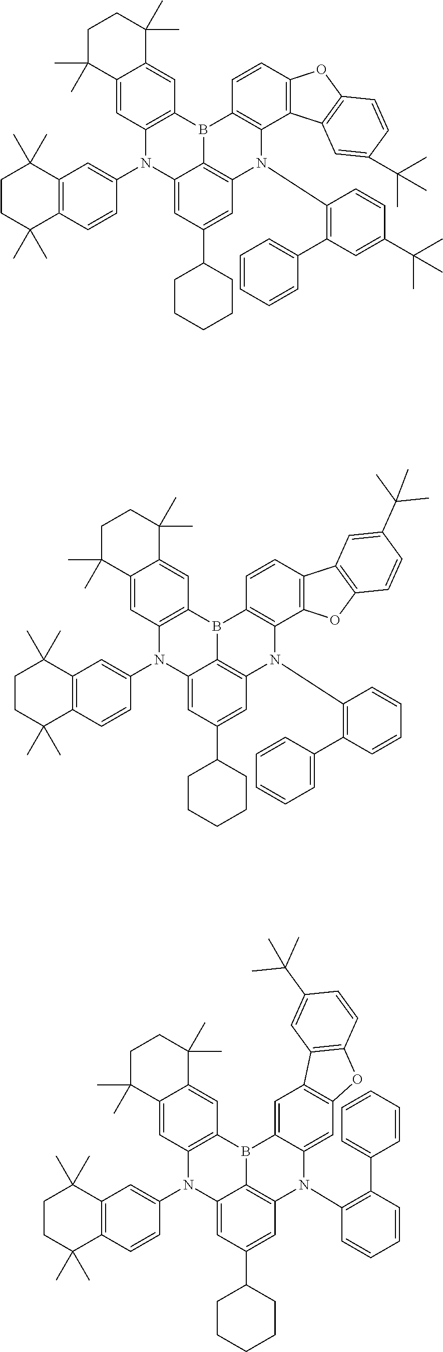 [SMILES: CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4oc5ccc(C(C)(C)C)cc5c4c32)c(-c2ccccc2)c1 ; CC(C)(C)c1ccc2oc3c4c(ccc3c2c1)B1c2cc3c(cc2N(c2ccc5c(c2)C(C)(C)CCC5(C)C)c2cc(C5CCCCC5)cc(c21)N4c1ccccc1-c1ccccc1)C(C)(C)CCC3(C)C ; CC(C)(C)c1ccc2oc3cc4c(cc3c2c1)B1c2cc3c(cc2N(c2ccc5c(c2)C(C)(C)CCC5(C)C)c2cc(C5CCCCC5)cc(c21)N4c1ccccc1-c1ccccc1)C(C)(C)CCC3(C)C]

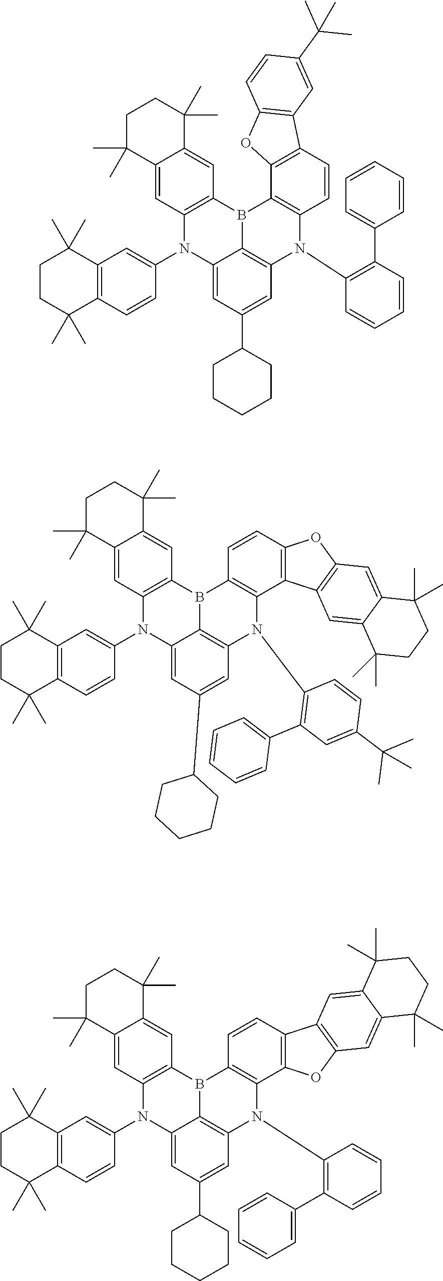 [SMILES: CC(C)(C)c1ccc2oc3c4c(ccc3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4oc5cc6c(cc5c4c32)C(C)(C)CCC6(C)C)c(-c2ccccc2)c1 ; CC1(C)CCC(C)(C)c2cc(N3c4cc5c(cc4B4c6ccc7c(oc8cc9c(cc87)C(C)(C)CCC9(C)C)c6N(c6ccccc6-c6ccccc6)c6cc(C7CCCCC7)cc3c64)C(C)(C)CCC5(C)C)ccc21]

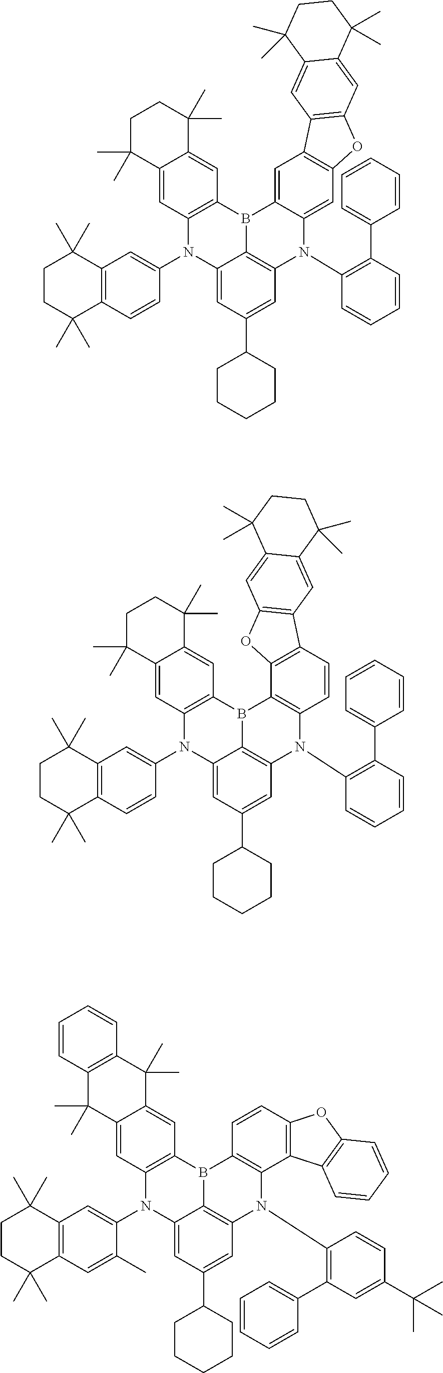 [SMILES: CC1(C)CCC(C)(C)c2cc(N3c4cc5c(cc4B4c6cc7c(cc6N(c6ccccc6-c6ccccc6)c6cc(C8CCCCC8)cc3c64)oc3cc4c(cc37)C(C)(C)CCC4(C)C)C(C)(C)CCC5(C)C)ccc21 ; CC1(C)CCC(C)(C)c2cc(N3c4cc5c(cc4B4c6c3cc(C3CCCCC3)cc6N(c3ccccc3-c3ccccc3)c3ccc6c(oc7cc8c(cc76)C(C)(C)CCC8(C)C)c34)C(C)(C)CCC5(C)C)ccc21 ; Cc1cc2c(cc1N1c3cc4c(cc3B3c5ccc6oc7ccccc7c6c5N(c5ccc(C(C)(C)C)cc5-c5ccccc5)c5cc(C6CCCCC6)cc1c53)C(C)(C)c1ccccc1C4(C)C)C(C)(C)CCC2(C)C]

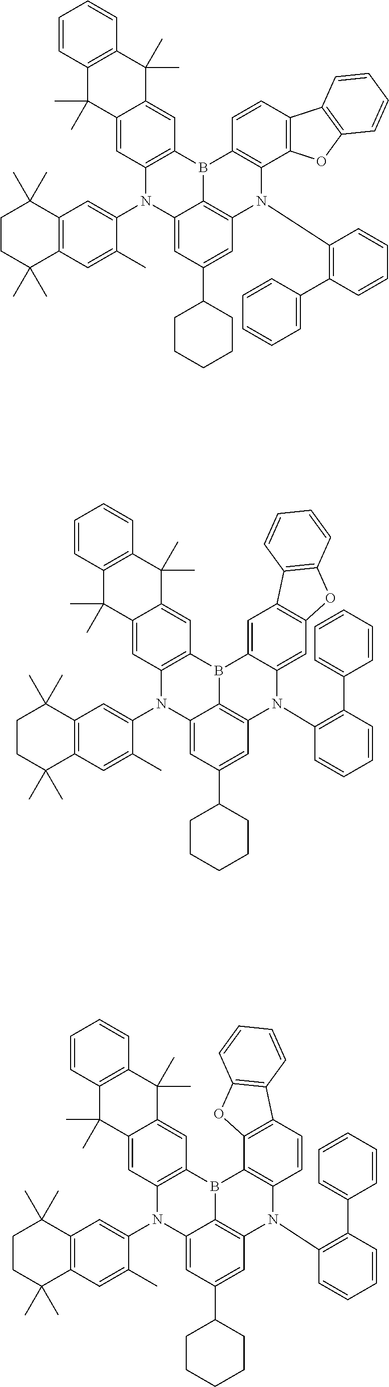 [SMILES: Cc1cc2c(cc1N1c3cc4c(cc3B3c5ccc6c(oc7ccccc76)c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C7CCCCC7)cc1c53)oc1ccccc16)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccccc1-c1ccccc1)c1ccc5c(oc6ccccc65)c13)C(C)(C)c1ccccc1C4(C)C)C(C)(C)CCC2(C)C]

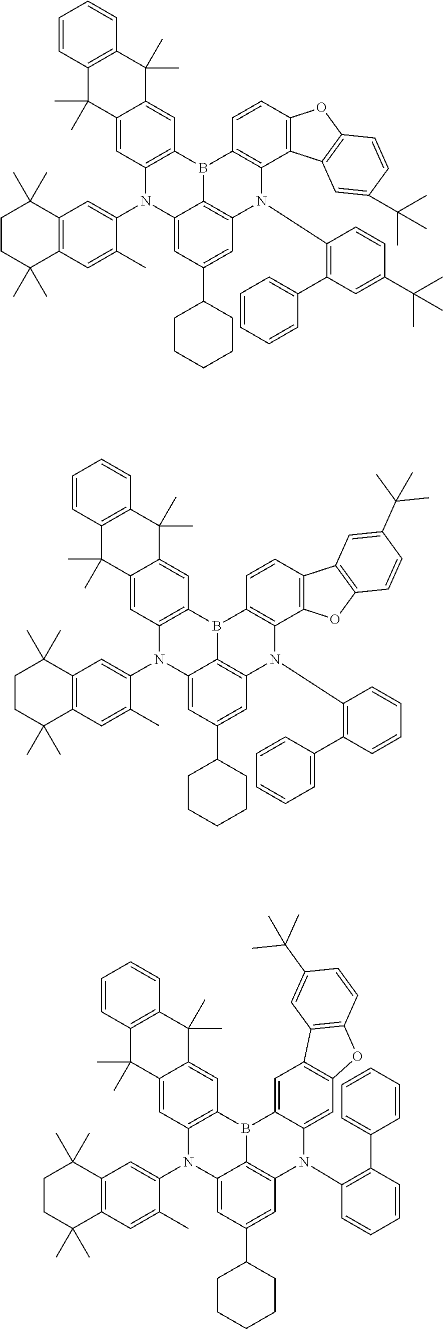 [SMILES: Cc1cc2c(cc1N1c3cc4c(cc3B3c5ccc6oc7ccc(C(C)(C)C)cc7c6c5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C7CCCCC7)cc1c53)oc1ccc(C(C)(C)C)cc16)C(C)(C)c1ccccc1C4(C)C)C(C)(C)CCC2(C)C]

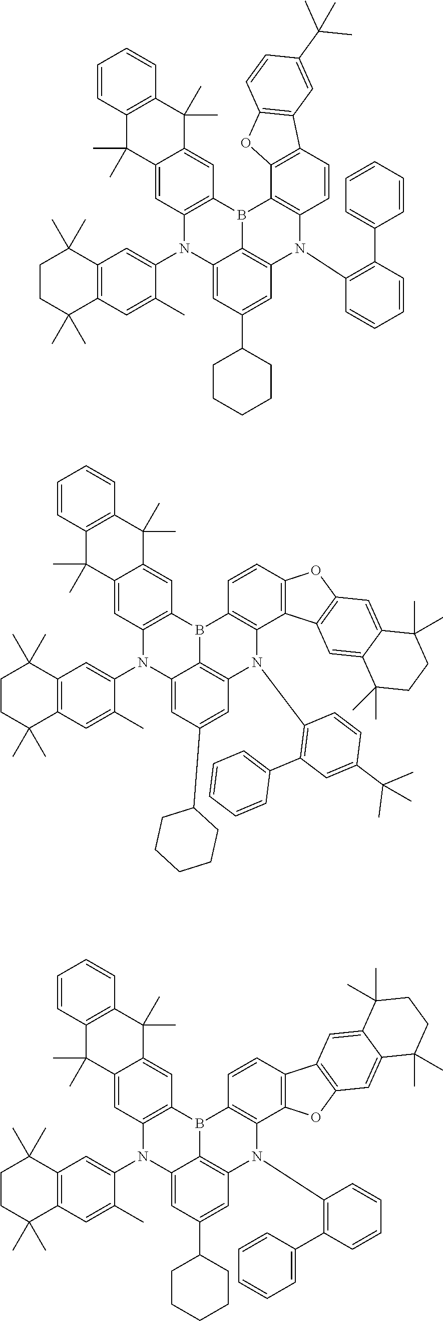 [SMILES: Cc1cc2c(cc1N1c3cc4c(cc3B3c5c1cc(C1CCCCC1)cc5N(c1ccccc1-c1ccccc1)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccc(C(C)(C)C)cc5-c5ccccc5)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5-c5ccccc5)c5cc(C6CCCCC6)cc1c53)C(C)(C)c1ccccc1C4(C)C)C(C)(C)CCC2(C)C]

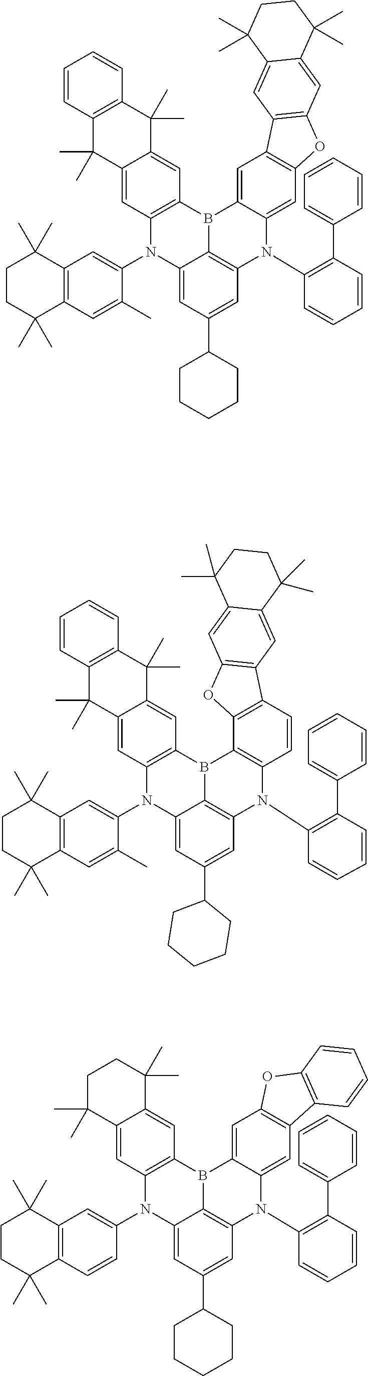 [SMILES: Cc1cc2c(cc1N1c3cc4c(cc3B3c5cc6c(cc5N(c5ccccc5-c5ccccc5)c5cc(C7CCCCC7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccccc1-c1ccccc1)c1ccc5c(oc6cc7c(cc65)C(C)(C)CCC7(C)C)c13)C(C)(C)c1ccccc1C4(C)C)C(C)(C)CCC2(C)C ; CC1(C)CCC(C)(C)c2cc(N3c4cc5c(cc4B4c6cc7oc8ccccc8c7cc6N(c6ccccc6-c6ccccc6)c6cc(C7CCCCC7)cc3c64)C(C)(C)CCC5(C)C)ccc21]

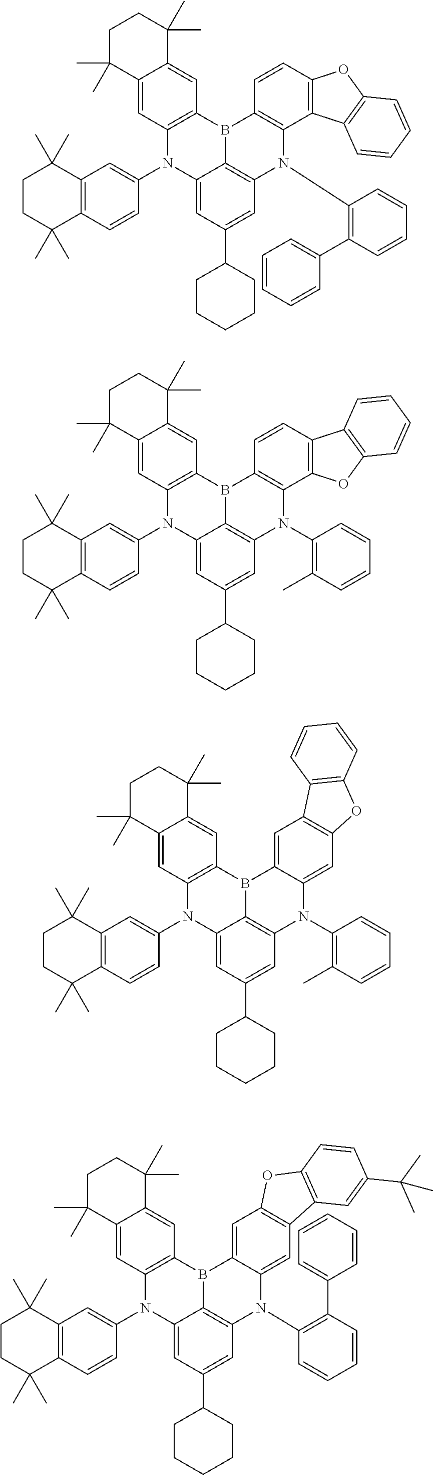 [SMILES: CC1(C)CCC(C)(C)c2cc(N3c4cc5c(cc4B4c6ccc7oc8ccccc8c7c6N(c6ccccc6-c6ccccc6)c6cc(C7CCCCC7)cc3c64)C(C)(C)CCC5(C)C)ccc21 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(oc4ccccc43)c21 ; Cc1ccccc1N1c2cc3oc4ccccc4c3cc2B2c3cc4c(cc3N(c3ccc5c(c3)C(C)(C)CCC5(C)C)c3cc(C5CCCCC5)cc1c32)C(C)(C)CCC4(C)C ; CC(C)(C)c1ccc2oc3cc4c(cc3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C]

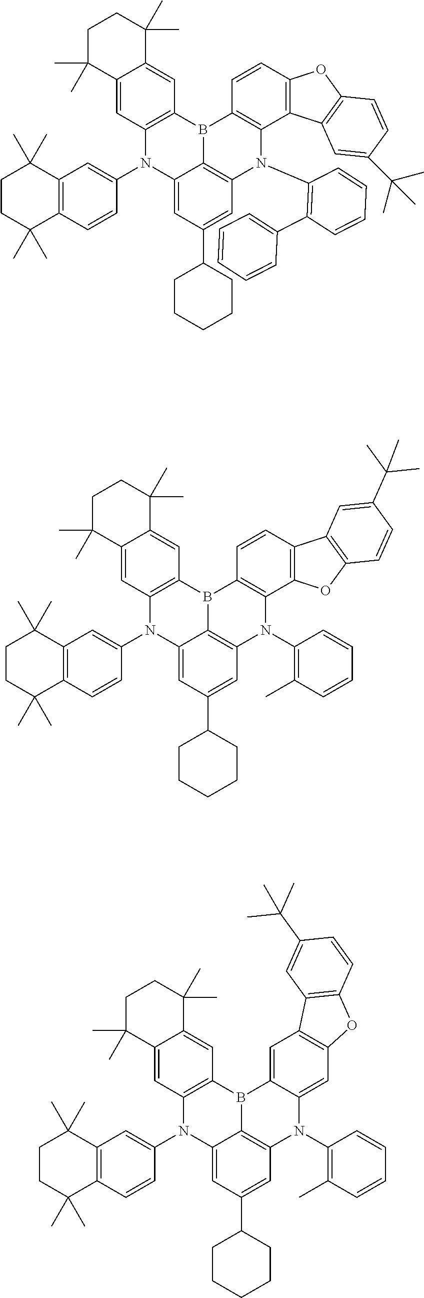 [SMILES: CC(C)(C)c1ccc2oc3ccc4c(c3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)CCC5(C)C)c3cc(C5CCCCC5)cc1c32)C(C)(C)CCC4(C)C]

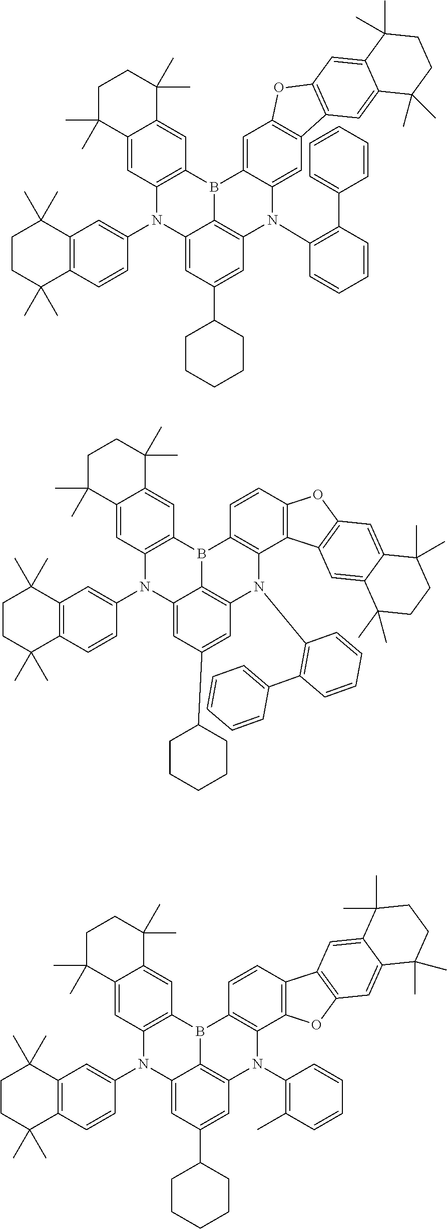 [SMILES: CC1(C)CCC(C)(C)c2cc(N3c4cc5c(cc4B4c6cc7oc8cc9c(cc8c7cc6N(c6ccccc6-c6ccccc6)c6cc(C7CCCCC7)cc3c64)C(C)(C)CCC9(C)C)C(C)(C)CCC5(C)C)ccc21 ; CC1(C)CCC(C)(C)c2cc(N3c4cc5c(cc4B4c6ccc7oc8cc9c(cc8c7c6N(c6ccccc6-c6ccccc6)c6cc(C7CCCCC7)cc3c64)C(C)(C)CCC9(C)C)C(C)(C)CCC5(C)C)ccc21 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(oc4cc5c(cc43)C(C)(C)CCC5(C)C)c21]

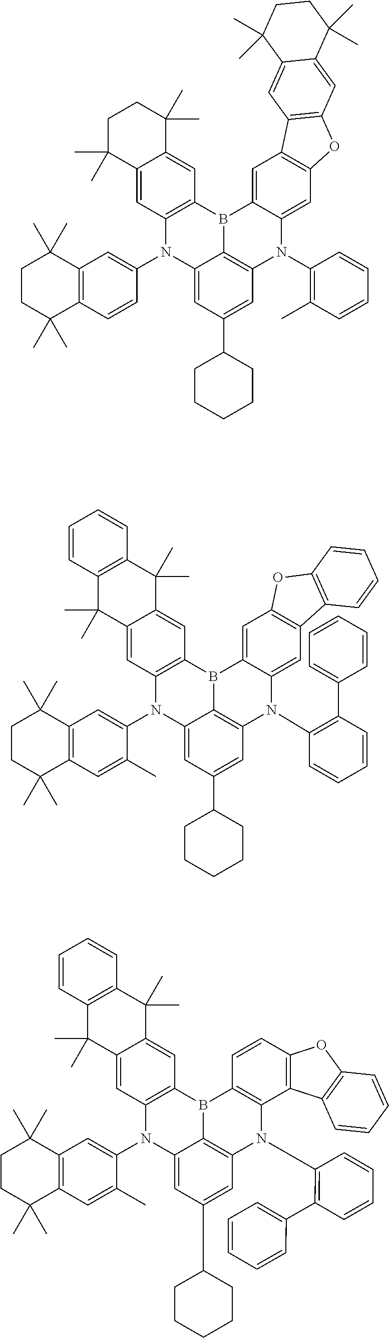 [SMILES: Cc1ccccc1N1c2cc3oc4cc5c(cc4c3cc2B2c3cc4c(cc3N(c3ccc6c(c3)C(C)(C)CCC6(C)C)c3cc(C6CCCCC6)cc1c32)C(C)(C)CCC4(C)C)C(C)(C)CCC5(C)C ; Cc1cc2c(cc1N1c3cc4c(cc3B3c5cc6oc7ccccc7c6cc5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(C6CCCCC6)cc1c53)C(C)(C)c1ccccc1C4(C)C)C(C)(C)CCC2(C)C]

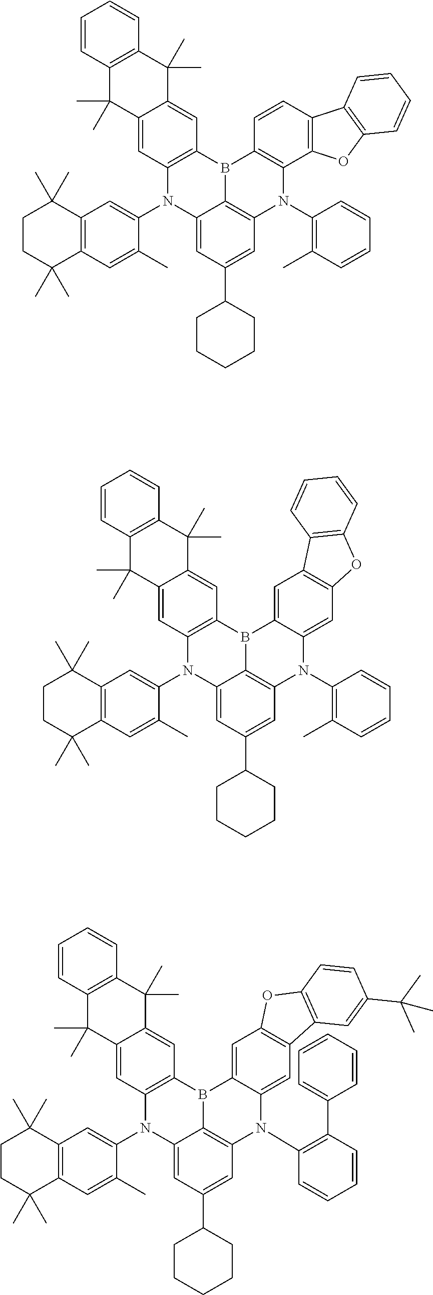 [SMILES: Cc1cc2c(cc1N1c3cc4c(cc3B3c5ccc6c(oc7ccccc76)c5N(c5ccccc5C)c5cc(C6CCCCC6)cc1c53)C(C)(C)c1ccccc1C4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(C5CCCCC5)cc1c32)C(C)(C)c1ccccc1C4(C)C ; Cc1cc2c(cc1N1c3cc4c(cc3B3c5cc6oc7ccc(C(C)(C)C)cc7c6cc5N(c5ccccc5-c5ccccc5)c5cc(C6CCCCC6)cc1c53)C(C)(C)c1ccccc1C4(C)C)C(C)(C)CCC2(C)C]

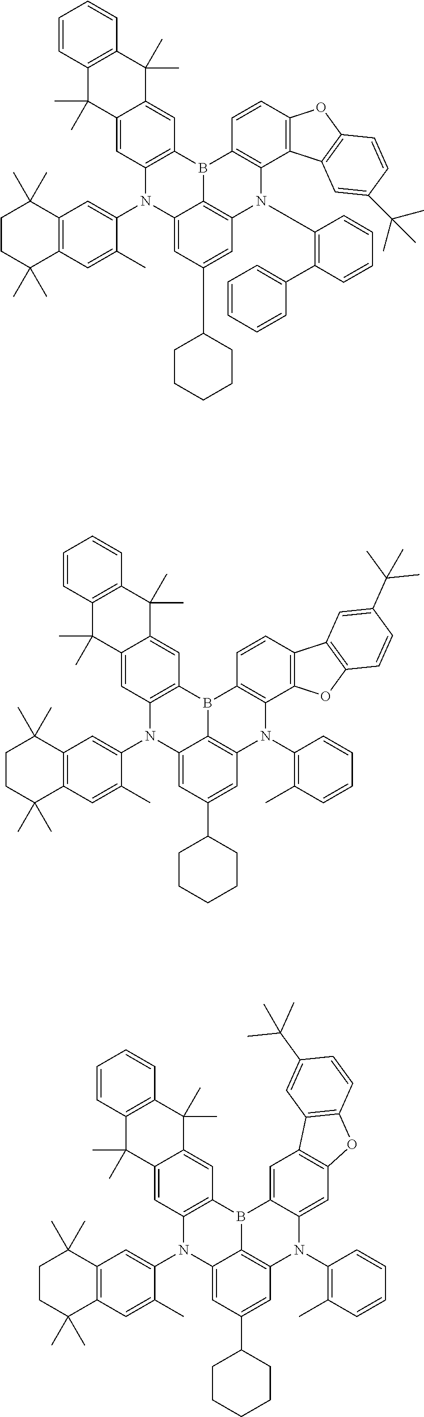 [SMILES: Cc1cc2c(cc1N1c3cc4c(cc3B3c5ccc6oc7ccc(C(C)(C)C)cc7c6c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5C)c5cc(C6CCCCC6)cc1c53)C(C)(C)c1ccccc1C4(C)C)C(C)(C)CCC2(C)C ; Cc1ccccc1N1c2cc3oc4ccc(C(C)(C)C)cc4c3cc2B2c3cc4c(cc3N(c3cc5c(cc3C)C(C)(C)CCC5(C)C)c3cc(C5CCCCC5)cc1c32)C(C)(C)c1ccccc1C4(C)C]

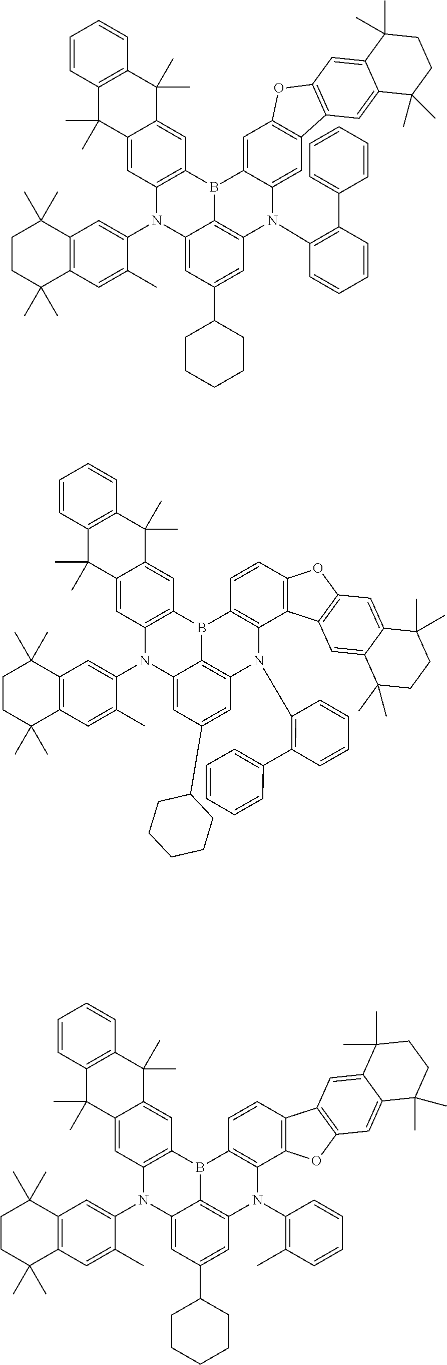 [SMILES: Cc1cc2c(cc1N1c3cc4c(cc3B3c5cc6oc7cc8c(cc7c6cc5N(c5ccccc5-c5ccccc5)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccccc5-c5ccccc5)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5C)c5cc(C6CCCCC6)cc1c53)C(C)(C)c1ccccc1C4(C)C)C(C)(C)CCC2(C)C]

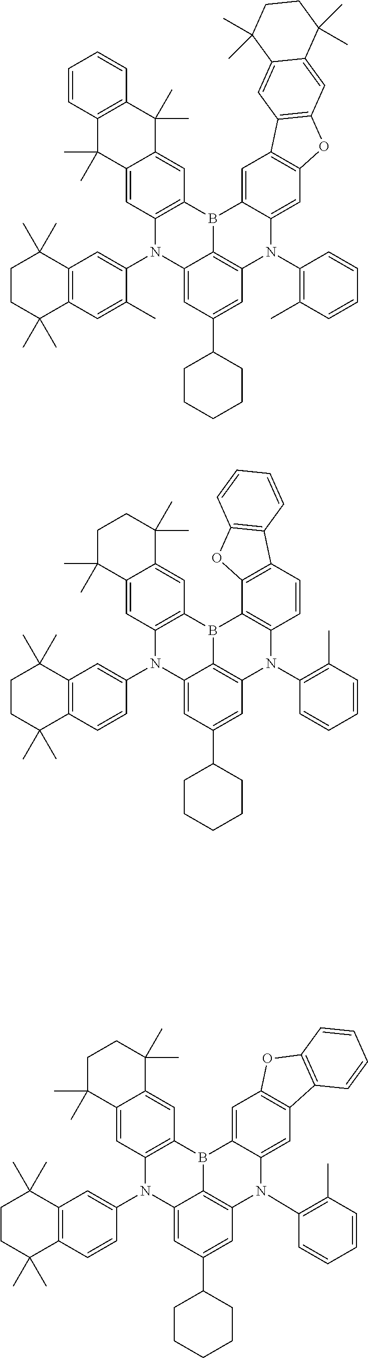 [SMILES: Cc1ccccc1N1c2cc3oc4cc5c(cc4c3cc2B2c3cc4c(cc3N(c3cc6c(cc3C)C(C)(C)CCC6(C)C)c3cc(C6CCCCC6)cc1c32)C(C)(C)c1ccccc1C4(C)C)C(C)(C)CCC5(C)C ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2c1ccc1c2oc2ccccc21 ; Cc1ccccc1N1c2cc3c(cc2B2c4cc5c(cc4N(c4ccc6c(c4)C(C)(C)CCC6(C)C)c4cc(C6CCCCC6)cc1c42)C(C)(C)CCC5(C)C)oc1ccccc13]

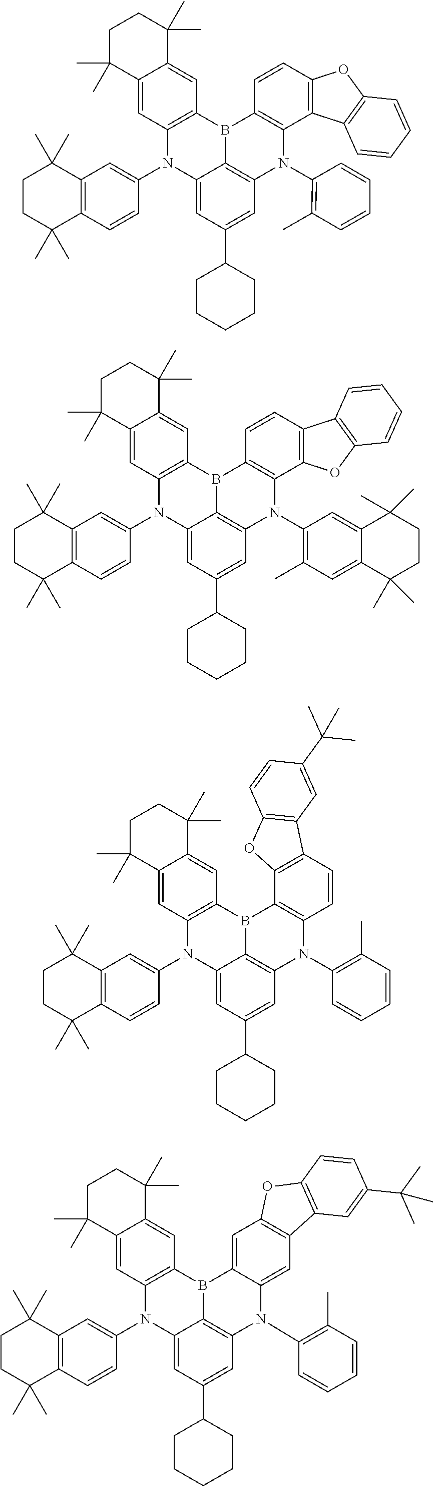

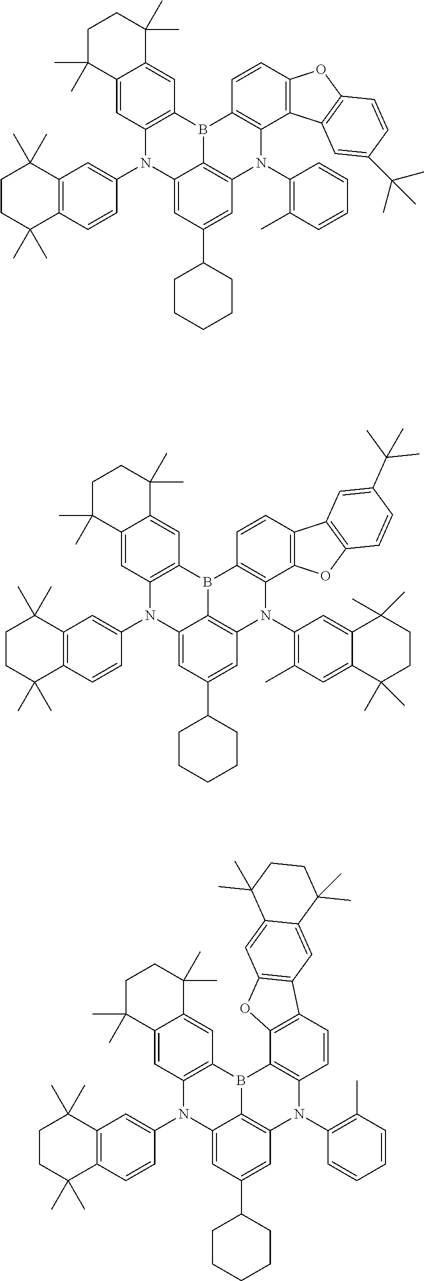 [SMILES: Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21 ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2c1ccc1c2oc2cc3c(cc21)C(C)(C)CCC3(C)C]

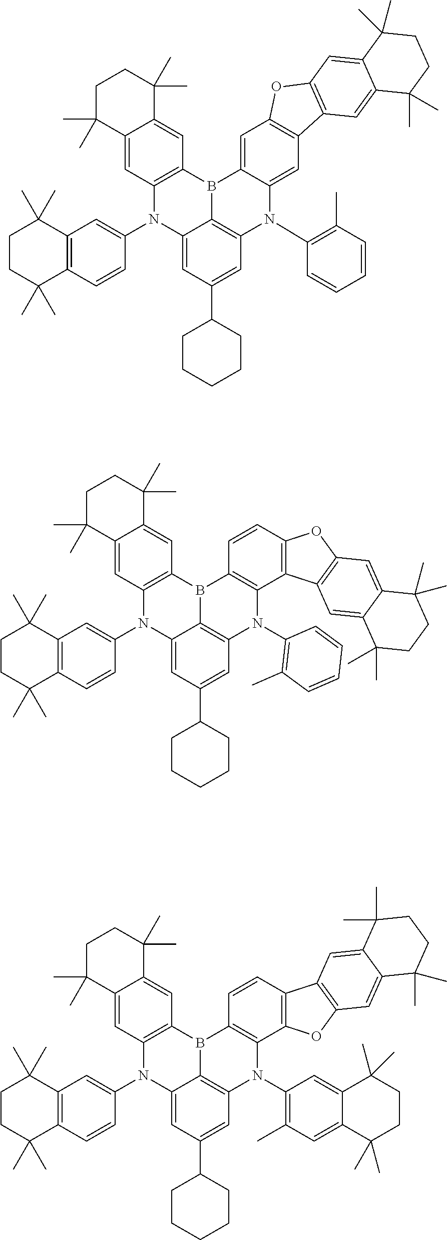 [SMILES: Cc1ccccc1N1c2cc3c(cc2B2c4cc5c(cc4N(c4ccc6c(c4)C(C)(C)CCC6(C)C)c4cc(C6CCCCC6)cc1c42)C(C)(C)CCC5(C)C)oc1cc2c(cc13)C(C)(C)CCC2(C)C ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3oc4cc5c(cc4c3c21)C(C)(C)CCC5(C)C ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c31)C(C)(C)CCC2(C)C]

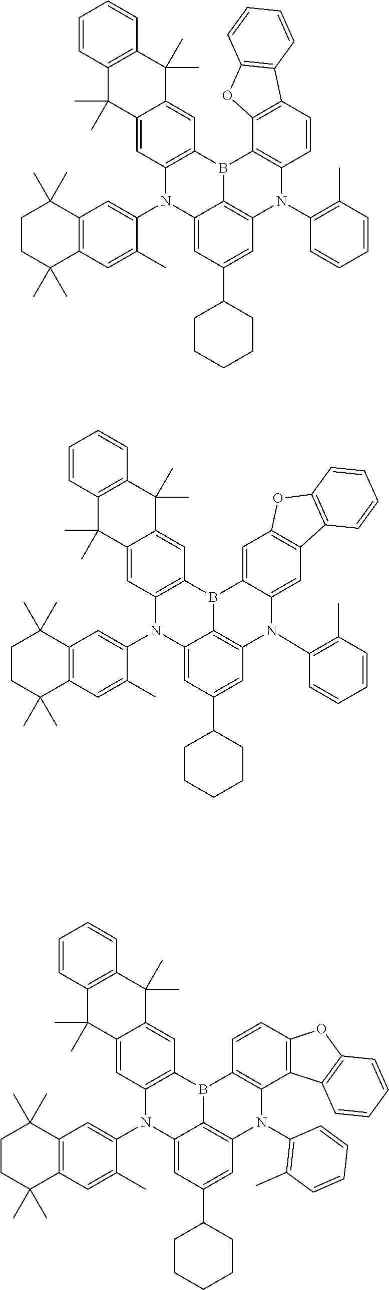 [SMILES: Cc1cc2c(cc1N1c3cc4c(cc3B3c5c1cc(C1CCCCC1)cc5N(c1ccccc1C)c1ccc5c(oc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)oc1ccccc13 ; Cc1cc2c(cc1N1c3cc4c(cc3B3c5ccc6oc7ccccc7c6c5N(c5ccccc5C)c5cc(C6CCCCC6)cc1c53)C(C)(C)c1ccccc1C4(C)C)C(C)(C)CCC2(C)C]

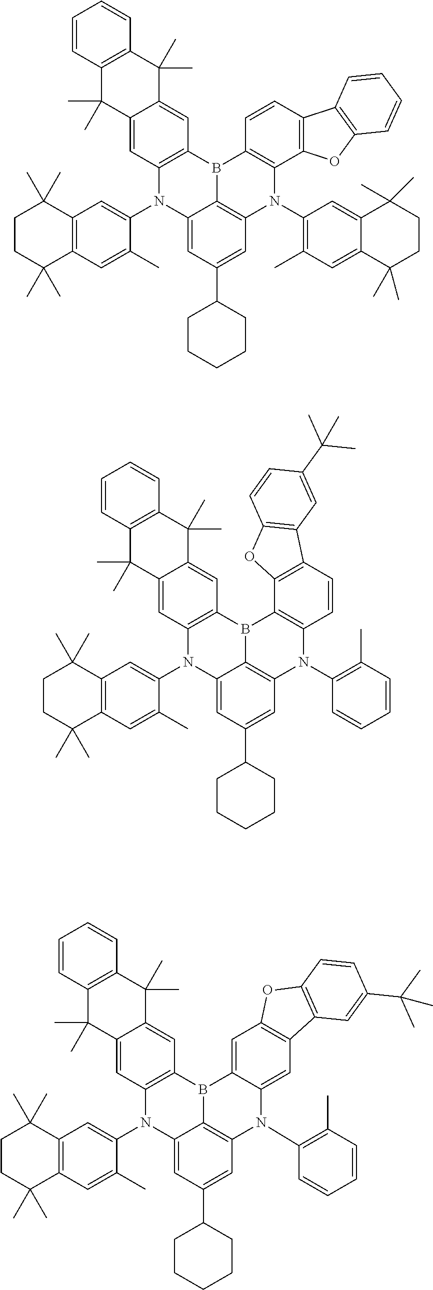 [SMILES: Cc1cc2c(cc1N1c3cc4c(cc3B3c5ccc6c(oc7ccccc76)c5N(c5cc6c(cc5C)C(C)(C)CCC6(C)C)c5cc(C6CCCCC6)cc1c53)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccccc1C)c1ccc5c(oc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)oc1ccc(C(C)(C)C)cc13]

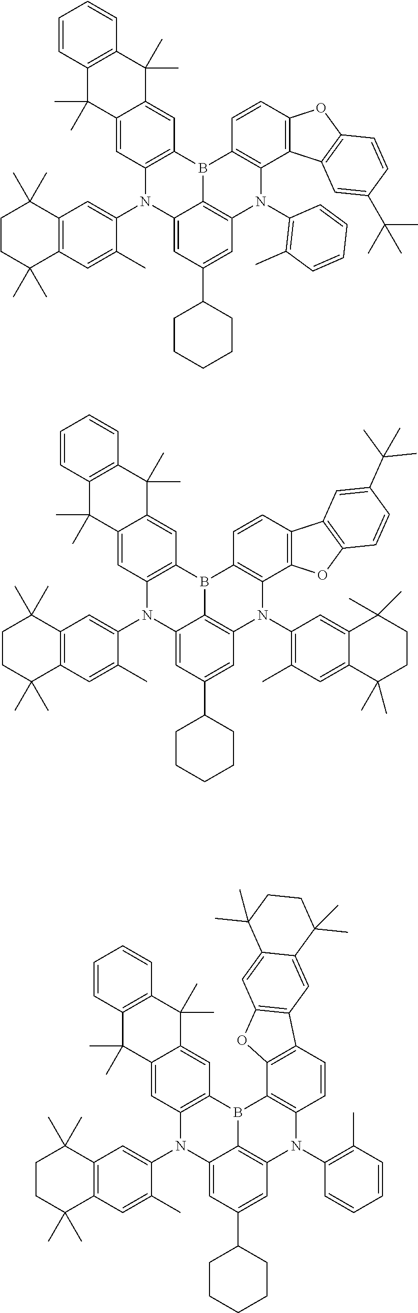 [SMILES: Cc1cc2c(cc1N1c3cc4c(cc3B3c5ccc6oc7ccc(C(C)(C)C)cc7c6c5N(c5ccccc5C)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(C6CCCCC6)cc1c53)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccccc1C)c1ccc5c(oc6cc7c(cc65)C(C)(C)CCC7(C)C)c13)C(C)(C)c1ccccc1C4(C)C)C(C)(C)CCC2(C)C]

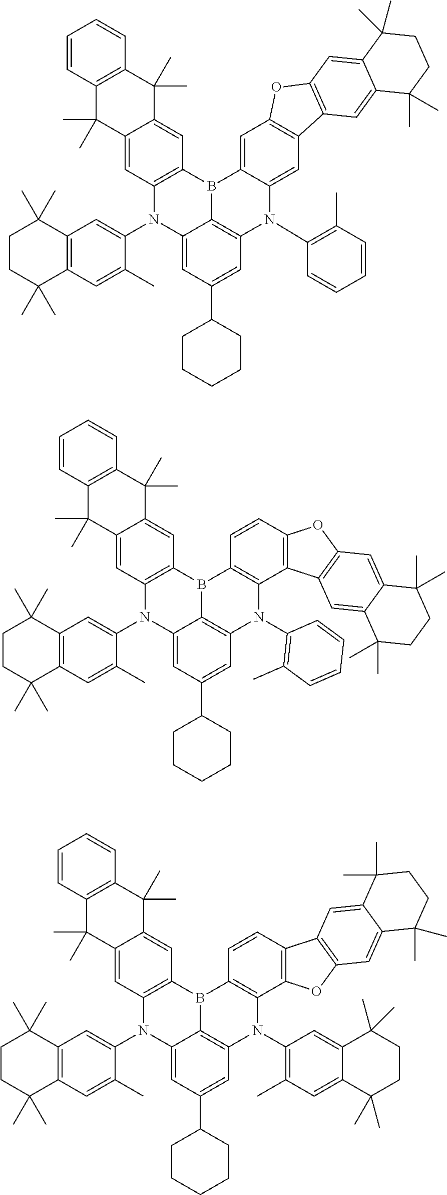 [SMILES: Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)oc1cc2c(cc13)C(C)(C)CCC2(C)C ; Cc1cc2c(cc1N1c3cc4c(cc3B3c5ccc6oc7cc8c(cc7c6c5N(c5ccccc5C)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5cc6c(cc5C)C(C)(C)CCC6(C)C)c5cc(C6CCCCC6)cc1c53)C(C)(C)c1ccccc1C4(C)C)C(C)(C)CCC2(C)C]

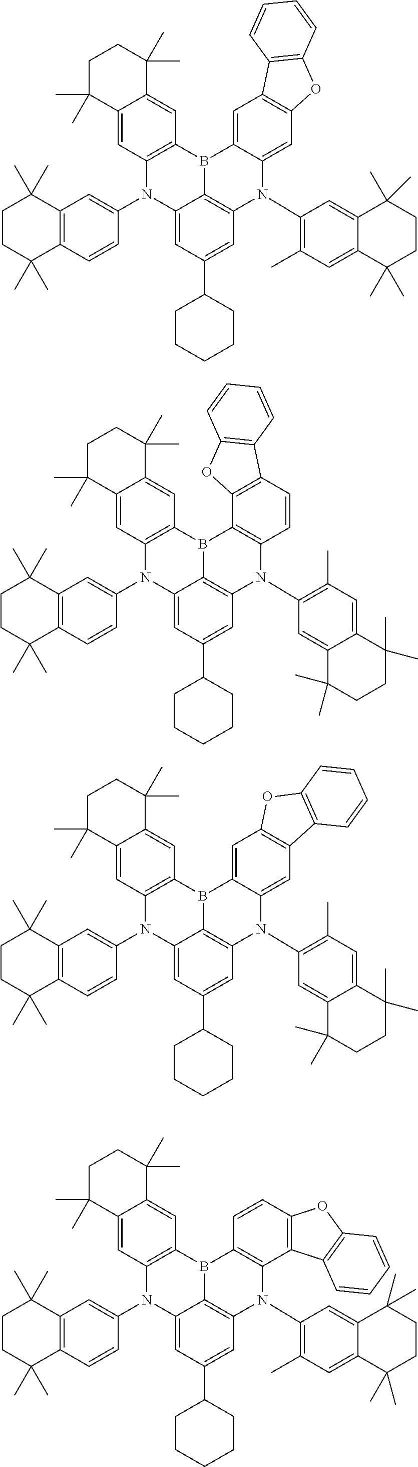

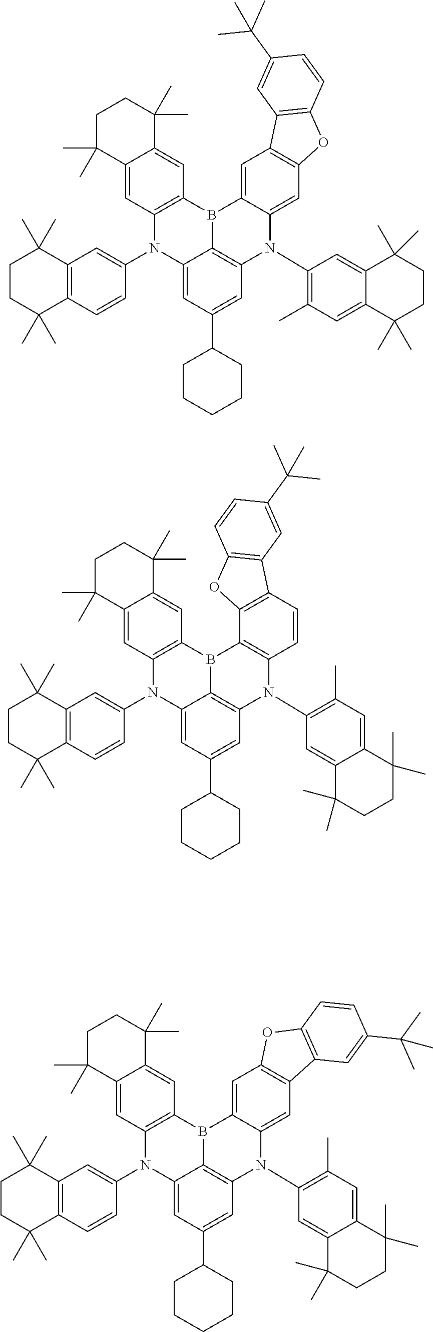 [SMILES: Cc1cc2c(cc1N1c3cc4oc5ccc(C(C)(C)C)cc5c4cc3B3c4cc5c(cc4N(c4ccc6c(c4)C(C)(C)CCC6(C)C)c4cc(C6CCCCC6)cc1c43)C(C)(C)CCC5(C)C)C(C)(C)CCC2(C)C ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3c1ccc1c3oc3ccc(C(C)(C)C)cc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(C7CCCCC7)cc1c53)C(C)(C)CCC6(C)C)oc1ccc(C(C)(C)C)cc14)C(C)(C)CCC2(C)C]

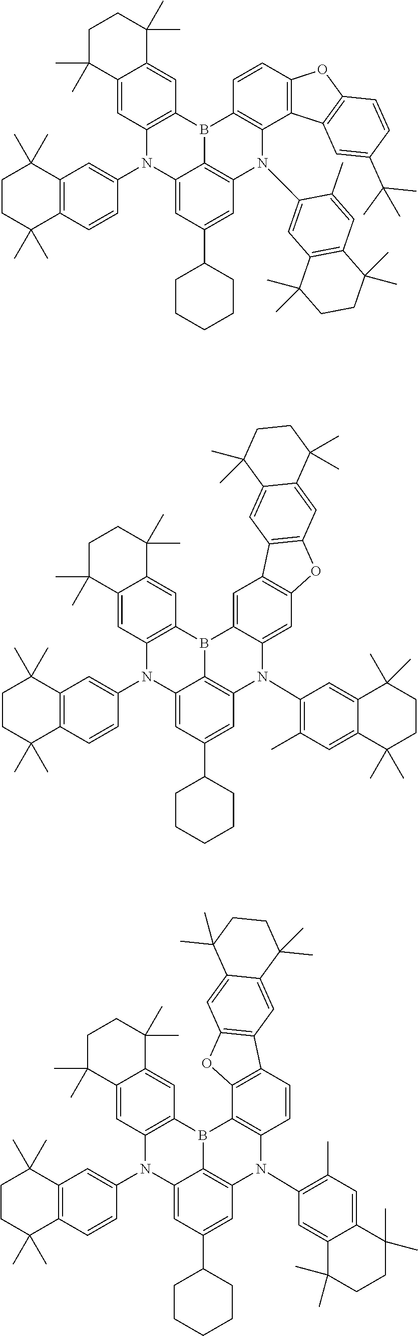 [SMILES: Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4oc5ccc(C(C)(C)C)cc5c4c31)C(C)(C)CCC2(C)C ; Cc1cc2c(cc1N1c3cc4oc5cc6c(cc5c4cc3B3c4cc5c(cc4N(c4ccc7c(c4)C(C)(C)CCC7(C)C)c4cc(C7CCCCC7)cc1c43)C(C)(C)CCC5(C)C)C(C)(C)CCC6(C)C)C(C)(C)CCC2(C)C ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3c1ccc1c3oc3cc4c(cc31)C(C)(C)CCC4(C)C)C(C)(C)CCC2(C)C]

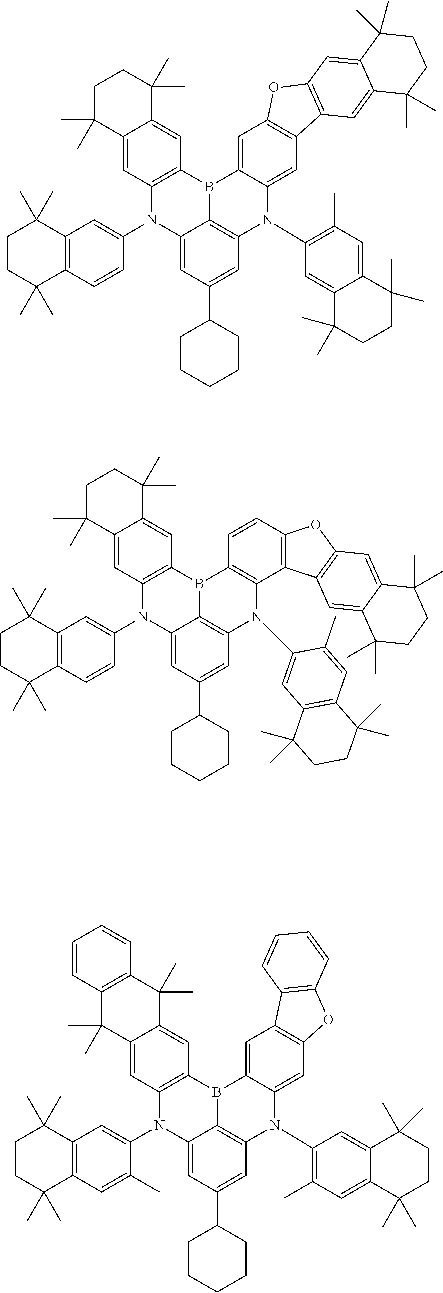 [SMILES: Cc1cc2c(cc1N1c3cc4c(cc3B3c5cc6c(cc5N(c5ccc7c(c5)C(C)(C)CCC7(C)C)c5cc(C7CCCCC7)cc1c53)C(C)(C)CCC6(C)C)oc1cc3c(cc14)C(C)(C)CCC3(C)C)C(C)(C)CCC2(C)C ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4oc5cc6c(cc5c4c31)C(C)(C)CCC6(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C7CCCCC7)cc1c53)oc1ccccc16)C(C)(C)c1ccccc1C4(C)C)C(C)(C)CCC2(C)C]

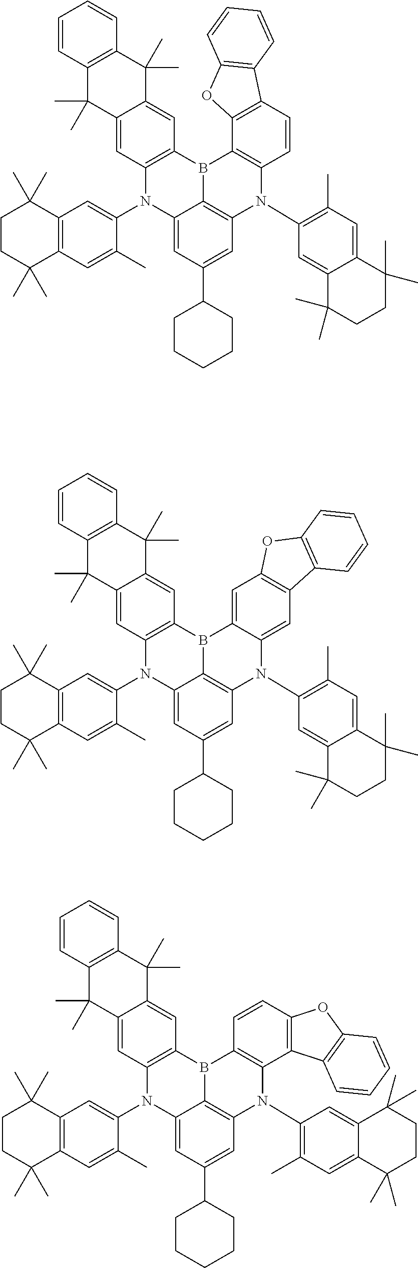 [SMILES: Cc1cc2c(cc1N1c3cc4c(cc3B3c5c1cc(C1CCCCC1)cc5N(c1cc5c(cc1C)C(C)(C)CCC5(C)C)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5cc6c(cc5C)C(C)(C)CCC6(C)C)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5cc6c(cc5C)C(C)(C)CCC6(C)C)c5cc(C6CCCCC6)cc1c53)C(C)(C)c1ccccc1C4(C)C)C(C)(C)CCC2(C)C]

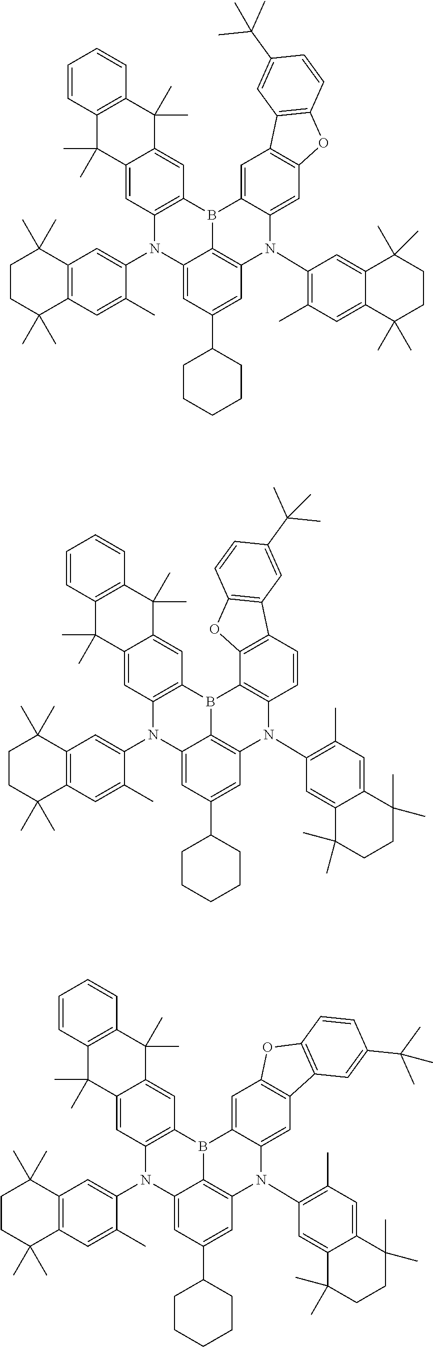 [SMILES: Cc1cc2c(cc1N1c3cc4c(cc3B3c5cc6c(cc5N(c5cc7c(cc5C)C(C)(C)CCC7(C)C)c5cc(C7CCCCC7)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C1CCCCC1)cc5N(c1cc5c(cc1C)C(C)(C)CCC5(C)C)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6oc7ccc(C(C)(C)C)cc7c6cc5N(c5cc6c(cc5C)C(C)(C)CCC6(C)C)c5cc(C6CCCCC6)cc1c53)C(C)(C)c1ccccc1C4(C)C)C(C)(C)CCC2(C)C]

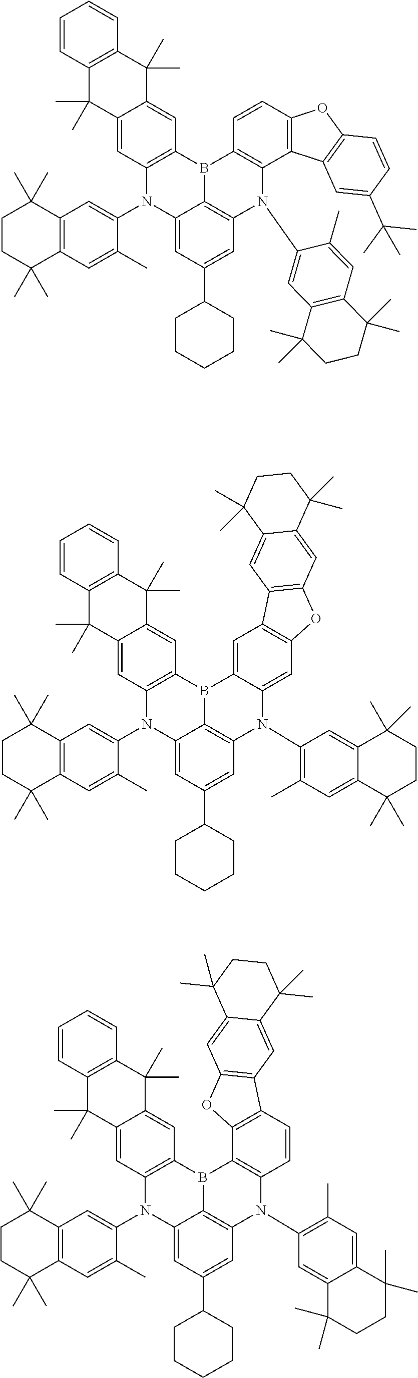 [SMILES: Cc1cc2c(cc1N1c3cc4c(cc3B3c5ccc6oc7ccc(C(C)(C)C)cc7c6c5N(c5cc6c(cc5C)C(C)(C)CCC6(C)C)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C7CCCCC7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C1CCCCC1)cc5N(c1cc5c(cc1C)C(C)(C)CCC5(C)C)c1ccc5c(oc6cc7c(cc65)C(C)(C)CCC7(C)C)c13)C(C)(C)c1ccccc1C4(C)C)C(C)(C)CCC2(C)C]

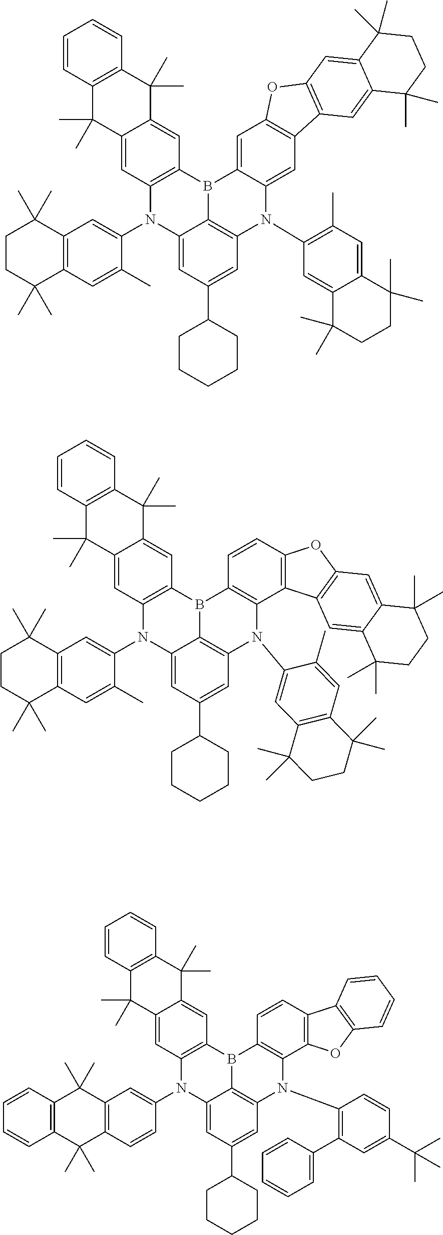 [SMILES: Cc1cc2c(cc1N1c3cc4c(cc3B3c5cc6oc7cc8c(cc7c6cc5N(c5cc6c(cc5C)C(C)(C)CCC6(C)C)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5cc6c(cc5C)C(C)(C)CCC6(C)C)c5cc(C6CCCCC6)cc1c53)C(C)(C)CCC8(C)C)C(C)(C)c1ccccc1C4(C)C)C(C)(C)CCC2(C)C ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(oc5ccccc54)c32)c(-c2ccccc2)c1]

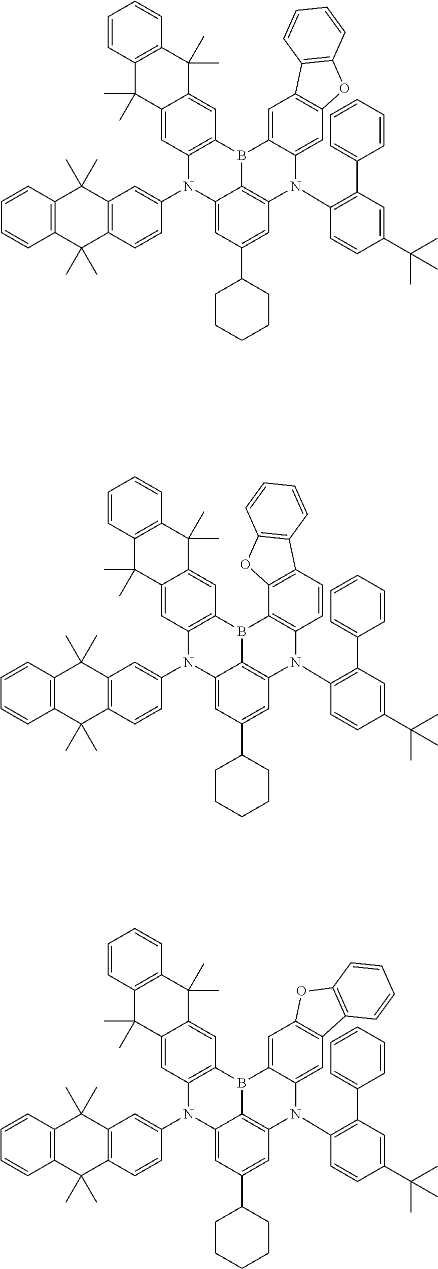 [SMILES: CC(C)(C)c1ccc(N2c3cc4oc5ccccc5c4cc3B3c4cc5c(cc4N(c4ccc6c(c4)C(C)(C)c4ccccc4C6(C)C)c4cc(C6CCCCC6)cc2c43)C(C)(C)c2ccccc2C5(C)C)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3c2ccc2c3oc3ccccc32)c(-c2ccccc2)c1 ; CC(C)(C)c1ccc(N2c3cc4c(cc3B3c5cc6c(cc5N(c5ccc7c(c5)C(C)(C)c5ccccc5C7(C)C)c5cc(C7CCCCC7)cc2c53)C(C)(C)c2ccccc2C6(C)C)oc2ccccc24)c(-c2ccccc2)c1]

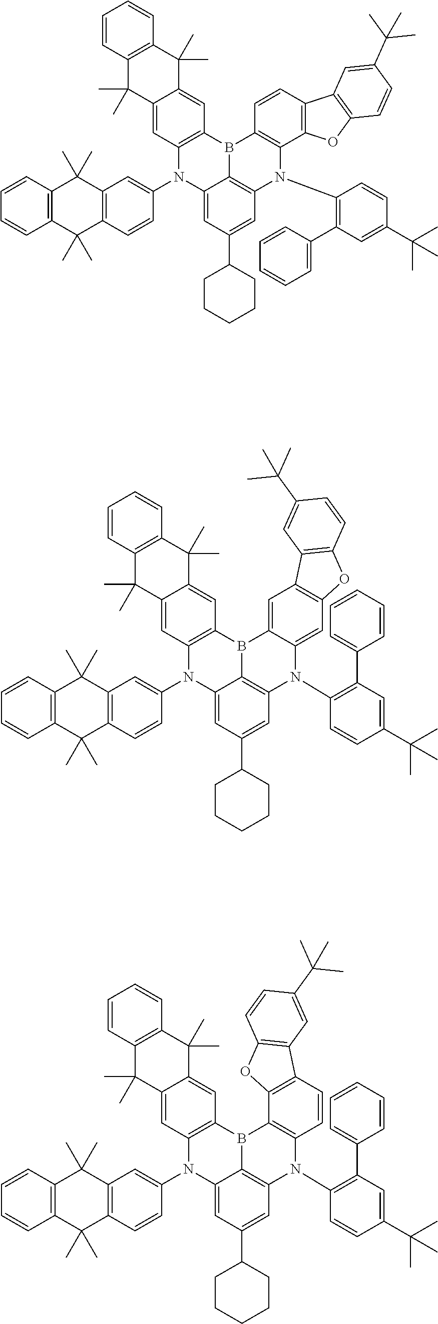 [SMILES: CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(oc5ccc(C(C)(C)C)cc54)c32)c(-c2ccccc2)c1 ; CC(C)(C)c1ccc(N2c3cc4oc5ccc(C(C)(C)C)cc5c4cc3B3c4cc5c(cc4N(c4ccc6c(c4)C(C)(C)c4ccccc4C6(C)C)c4cc(C6CCCCC6)cc2c43)C(C)(C)c2ccccc2C5(C)C)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3c2ccc2c3oc3ccc(C(C)(C)C)cc32)c(-c2ccccc2)c1]

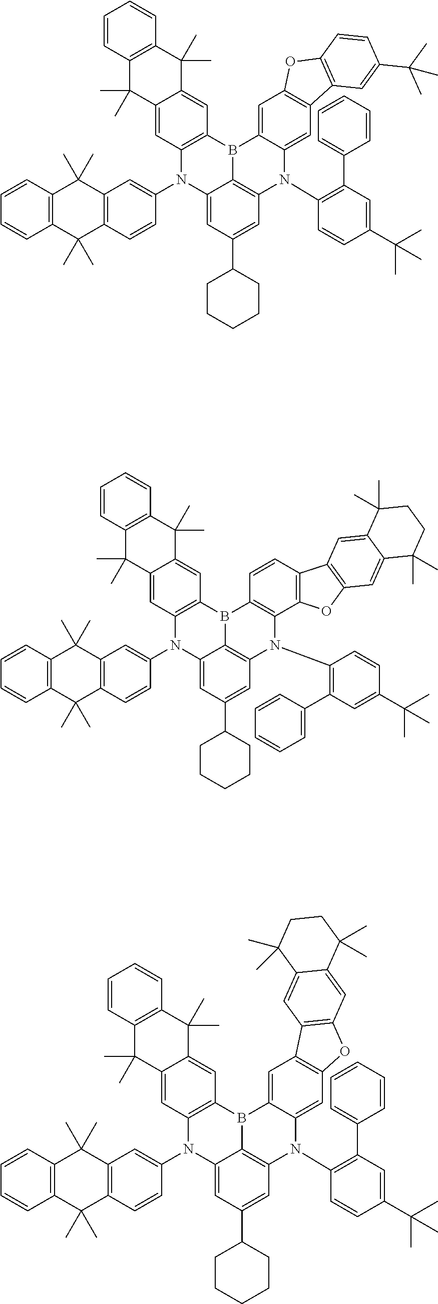 [SMILES: CC(C)(C)c1ccc(N2c3cc4c(cc3B3c5cc6c(cc5N(c5ccc7c(c5)C(C)(C)c5ccccc5C7(C)C)c5cc(C7CCCCC7)cc2c53)C(C)(C)c2ccccc2C6(C)C)oc2ccc(C(C)(C)C)cc24)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(oc5cc6c(cc54)C(C)(C)CCC6(C)C)c32)c(-c2ccccc2)c1 ; CC(C)(C)c1ccc(N2c3cc4oc5cc6c(cc5c4cc3B3c4cc5c(cc4N(c4ccc7c(c4)C(C)(C)c4ccccc4C7(C)C)c4cc(C7CCCCC7)cc2c43)C(C)(C)c2ccccc2C5(C)C)C(C)(C)CCC6(C)C)c(-c2ccccc2)c1]

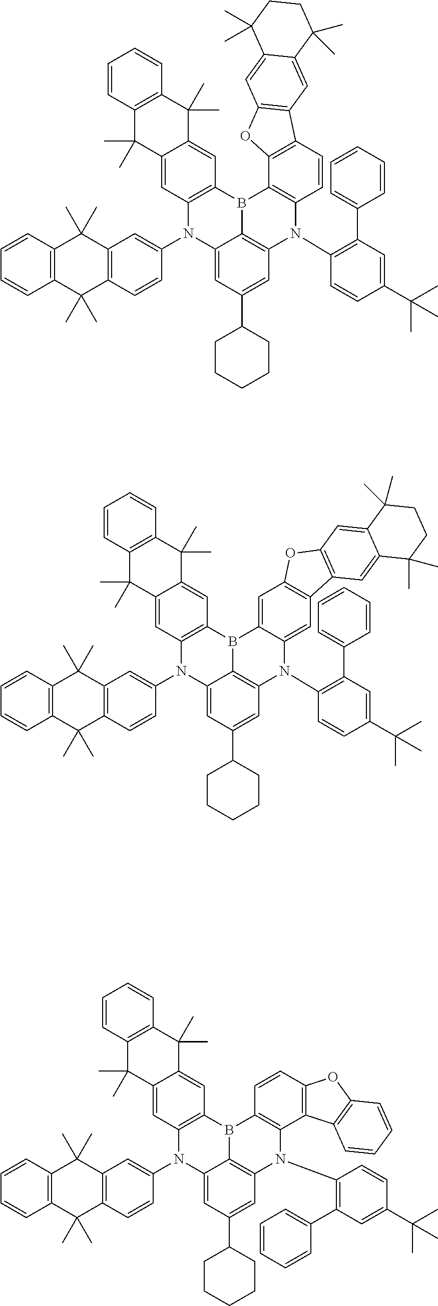 [SMILES: CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3c2ccc2c3oc3cc4c(cc32)C(C)(C)CCC4(C)C)c(-c2ccccc2)c1 ; CC(C)(C)c1ccc(N2c3cc4c(cc3B3c5cc6c(cc5N(c5ccc7c(c5)C(C)(C)c5ccccc5C7(C)C)c5cc(C7CCCCC7)cc2c53)C(C)(C)c2ccccc2C6(C)C)oc2cc3c(cc24)C(C)(C)CCC3(C)C)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4oc5ccccc5c4c32)c(-c2ccccc2)c1]

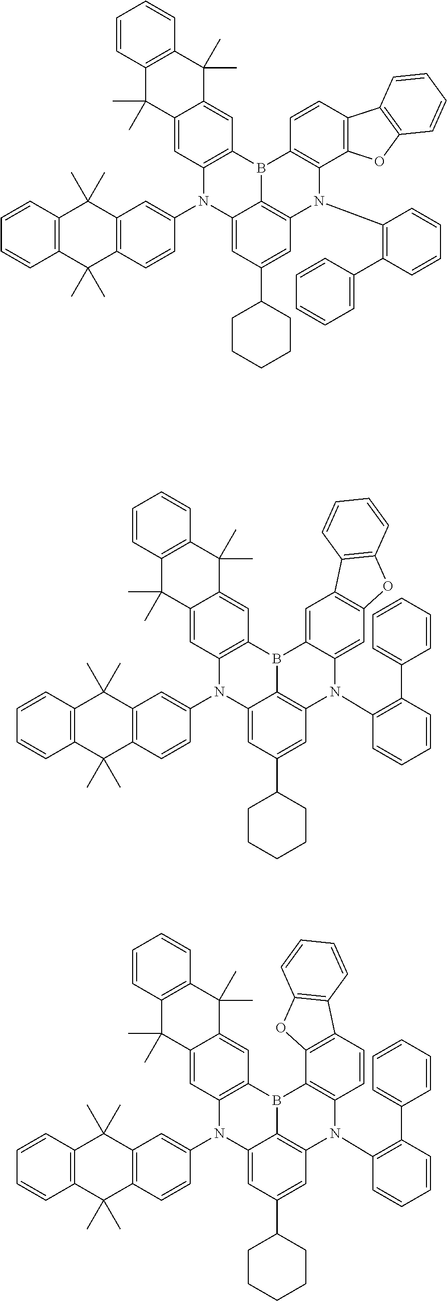 [SMILES: CC1(C)c2ccccc2C(C)(C)c2cc(N3c4cc5c(cc4B4c6ccc7c(oc8ccccc87)c6N(c6ccccc6-c6ccccc6)c6cc(C7CCCCC7)cc3c64)C(C)(C)c3ccccc3C5(C)C)ccc21 ; CC1(C)c2ccccc2C(C)(C)c2cc(N3c4cc5c(cc4B4c6cc7c(cc6N(c6ccccc6-c6ccccc6)c6cc(C8CCCCC8)cc3c64)oc3ccccc37)C(C)(C)c3ccccc3C5(C)C)ccc21 ; CC1(C)c2ccccc2C(C)(C)c2cc(N3c4cc5c(cc4B4c6c3cc(C3CCCCC3)cc6N(c3ccccc3-c3ccccc3)c3ccc6c(oc7ccccc76)c34)C(C)(C)c3ccccc3C5(C)C)ccc21]

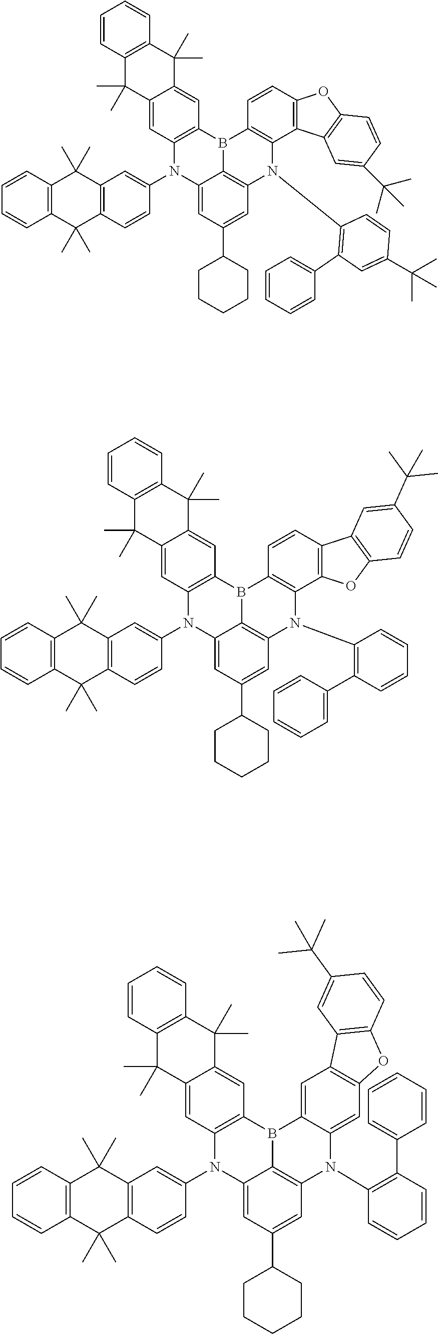 [SMILES: CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4oc5ccc(C(C)(C)C)cc5c4c32)c(-c2ccccc2)c1 ; CC(C)(C)c1ccc2oc3c4c(ccc3c2c1)B1c2cc3c(cc2N(c2ccc5c(c2)C(C)(C)c2ccccc2C5(C)C)c2cc(C5CCCCC5)cc(c21)N4c1ccccc1-c1ccccc1)C(C)(C)c1ccccc1C3(C)C ; CC(C)(C)c1ccc2oc3cc4c(cc3c2c1)B1c2cc3c(cc2N(c2ccc5c(c2)C(C)(C)c2ccccc2C5(C)C)c2cc(C5CCCCC5)cc(c21)N4c1ccccc1-c1ccccc1)C(C)(C)c1ccccc1C3(C)C]

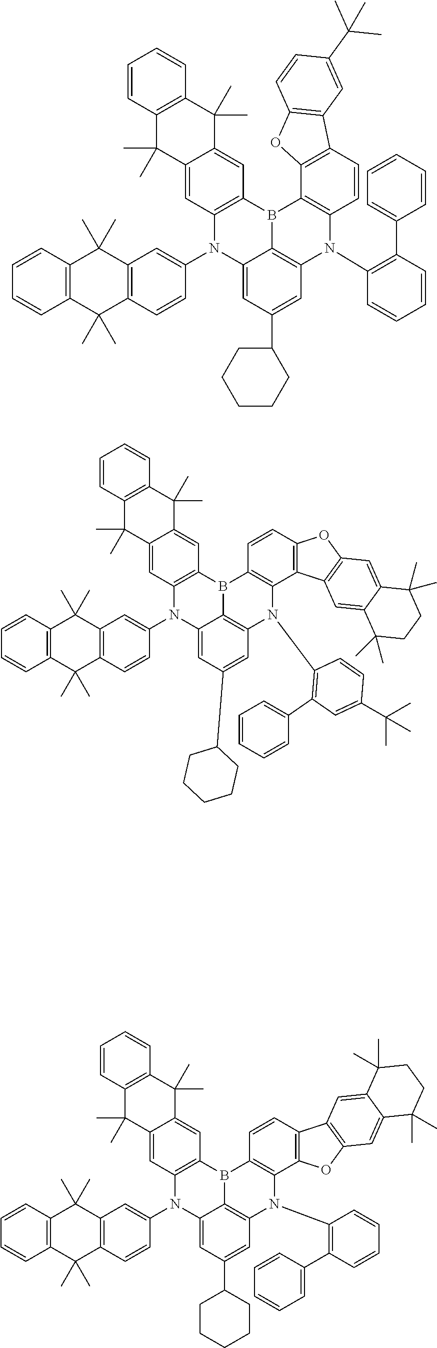 [SMILES: CC(C)(C)c1ccc2oc3c4c(ccc3c2c1)N(c1ccccc1-c1ccccc1)c1cc(C2CCCCC2)cc2c1B4c1cc3c(cc1N2c1ccc2c(c1)C(C)(C)c1ccccc1C2(C)C)C(C)(C)c1ccccc1C3(C)C ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4oc5cc6c(cc5c4c32)C(C)(C)CCC6(C)C)c(-c2ccccc2)c1 ; CC1(C)CCC(C)(C)c2cc3c(cc21)oc1c2c(ccc13)B1c3cc4c(cc3N(c3ccc5c(c3)C(C)(C)c3ccccc3C5(C)C)c3cc(C5CCCCC5)cc(c31)N2c1ccccc1-c1ccccc1)C(C)(C)c1ccccc1C4(C)C]

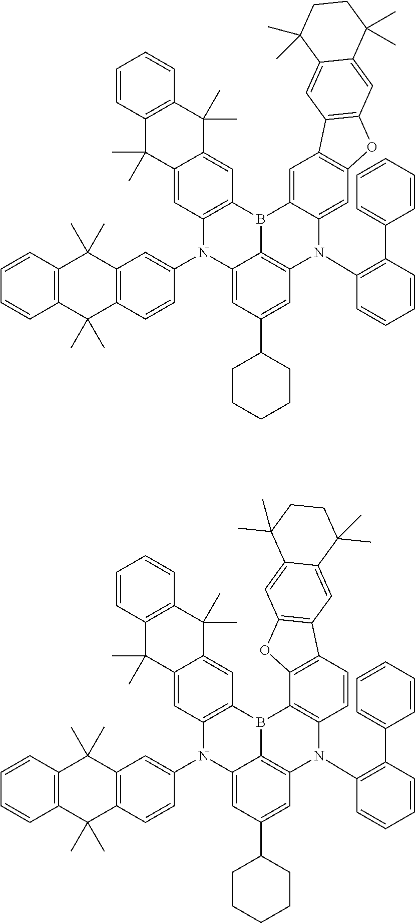 [SMILES: CC1(C)CCC(C)(C)c2cc3c(cc21)oc1cc2c(cc13)B1c3cc4c(cc3N(c3ccc5c(c3)C(C)(C)c3ccccc3C5(C)C)c3cc(C5CCCCC5)cc(c31)N2c1ccccc1-c1ccccc1)C(C)(C)c1ccccc1C4(C)C ; CC1(C)CCC(C)(C)c2cc3c(cc21)oc1c2c(ccc13)N(c1ccccc1-c1ccccc1)c1cc(C3CCCCC3)cc3c1B2c1cc2c(cc1N3c1ccc3c(c1)C(C)(C)c1ccccc1C3(C)C)C(C)(C)c1ccccc1C2(C)C]

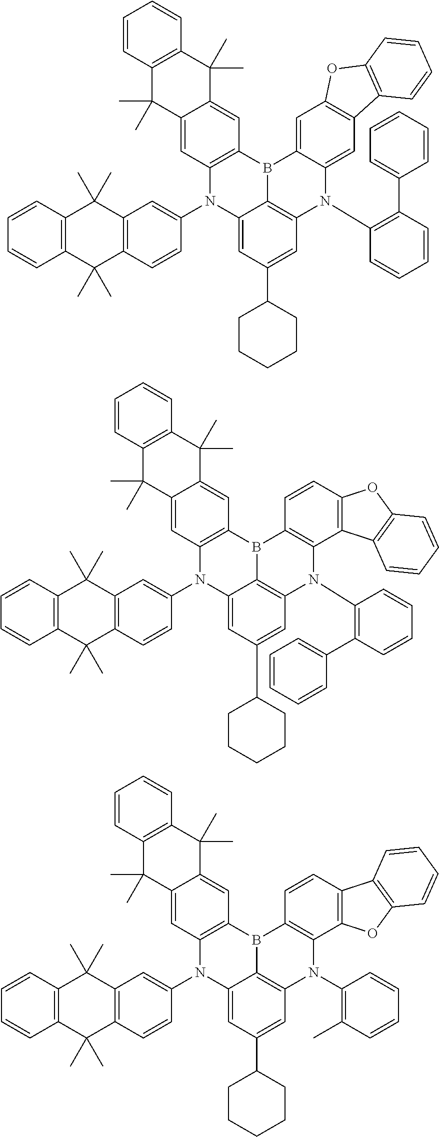 [SMILES: CC1(C)c2ccccc2C(C)(C)c2cc(N3c4cc5c(cc4B4c6cc7oc8ccccc8c7cc6N(c6ccccc6-c6ccccc6)c6cc(C7CCCCC7)cc3c64)C(C)(C)c3ccccc3C5(C)C)ccc21 ; CC1(C)c2ccccc2C(C)(C)c2cc(N3c4cc5c(cc4B4c6ccc7oc8ccccc8c7c6N(c6ccccc6-c6ccccc6)c6cc(C7CCCCC7)cc3c64)C(C)(C)c3ccccc3C5(C)C)ccc21 ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3c(oc4ccccc43)c21]

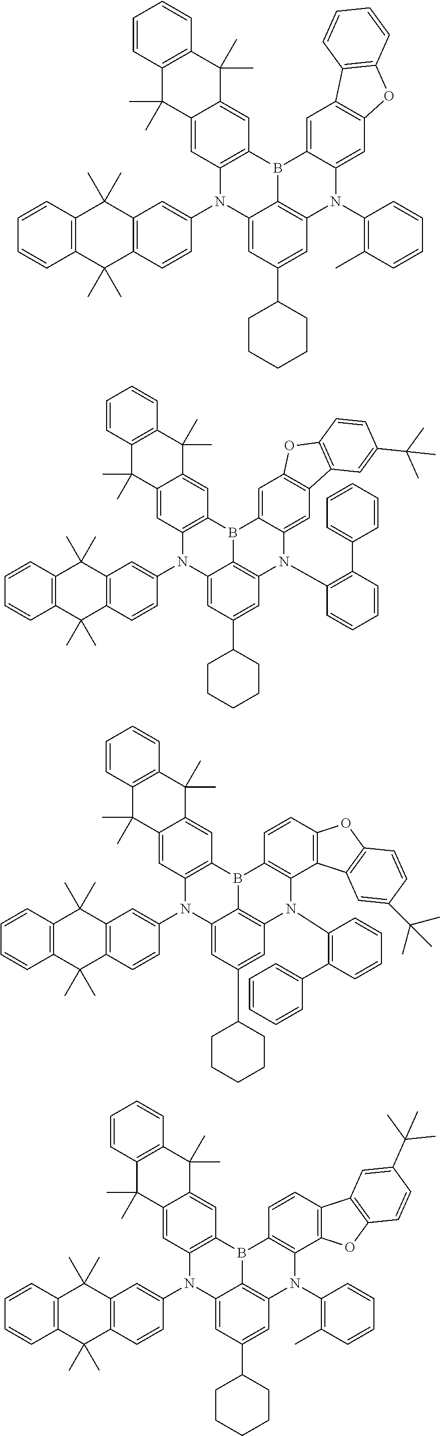

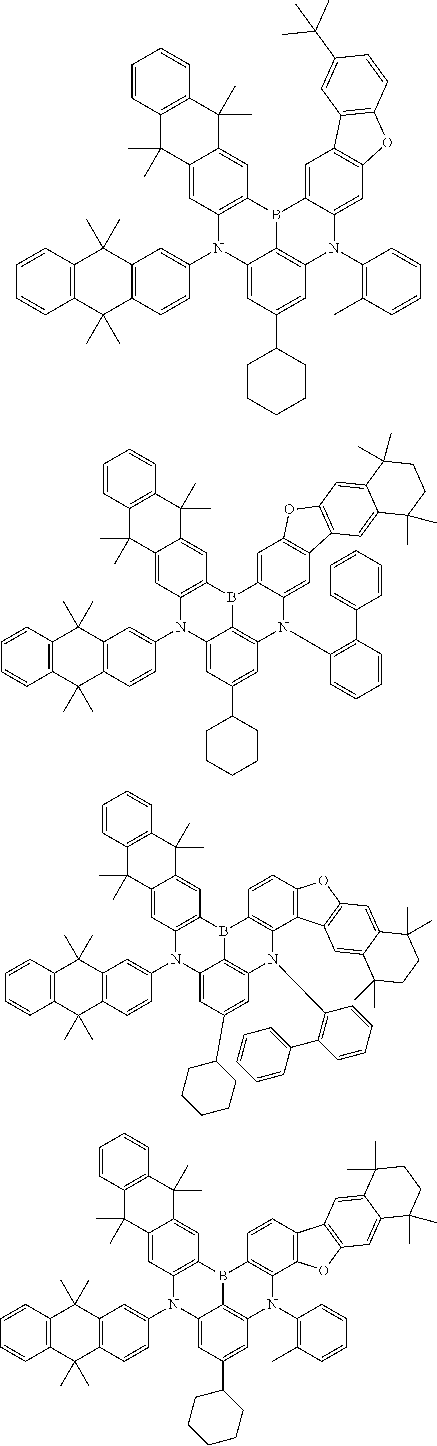

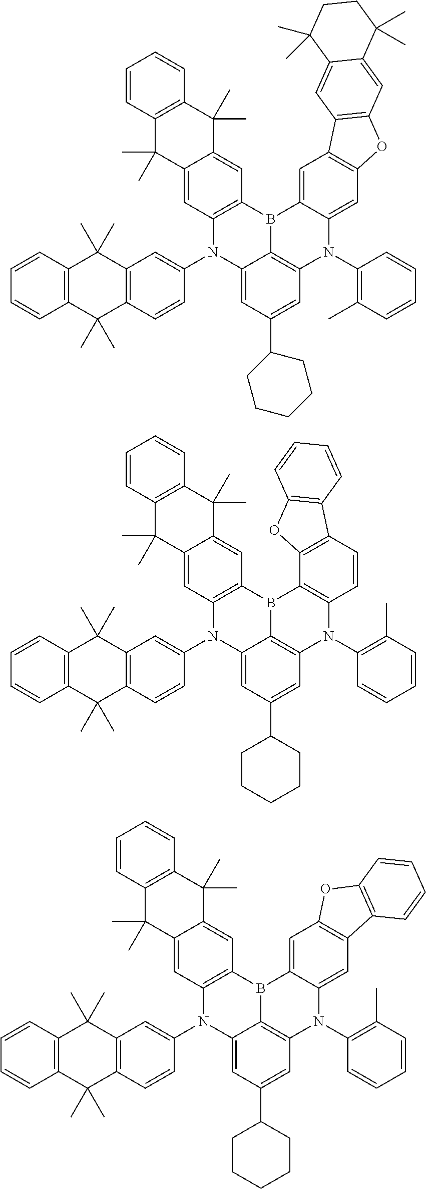

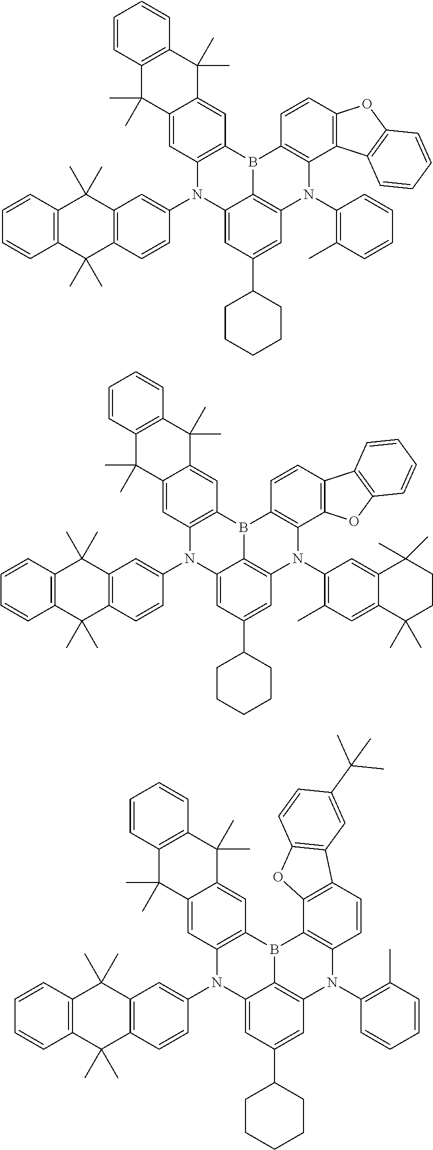 [SMILES: Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3oc4ccccc4c3c21 ; Cc1cc2c(cc1N1c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(oc5ccccc54)c31)C(C)(C)CCC2(C)C ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2c1ccc1c2oc2ccc(C(C)(C)C)cc21]

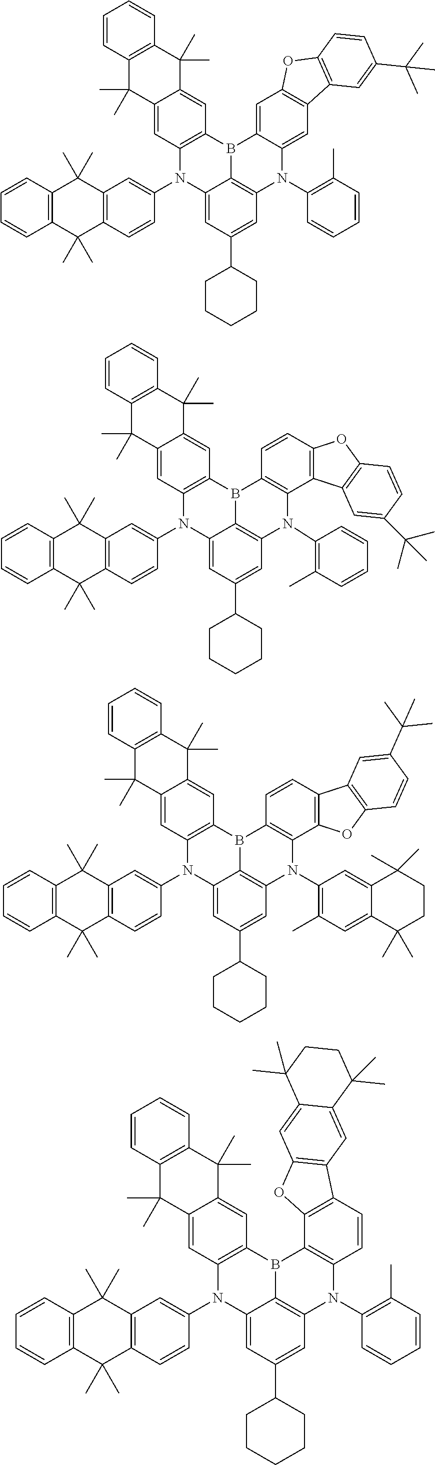

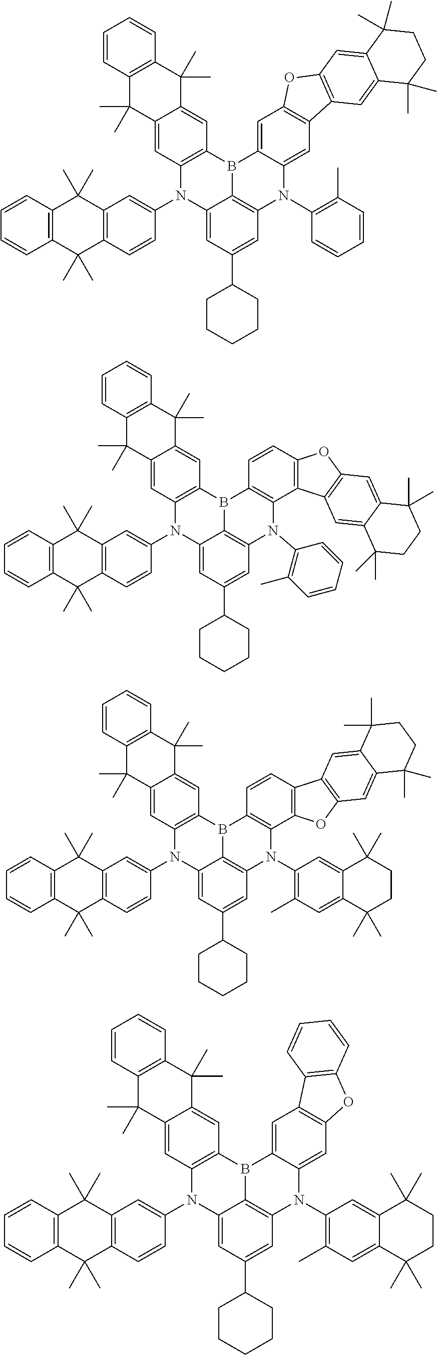

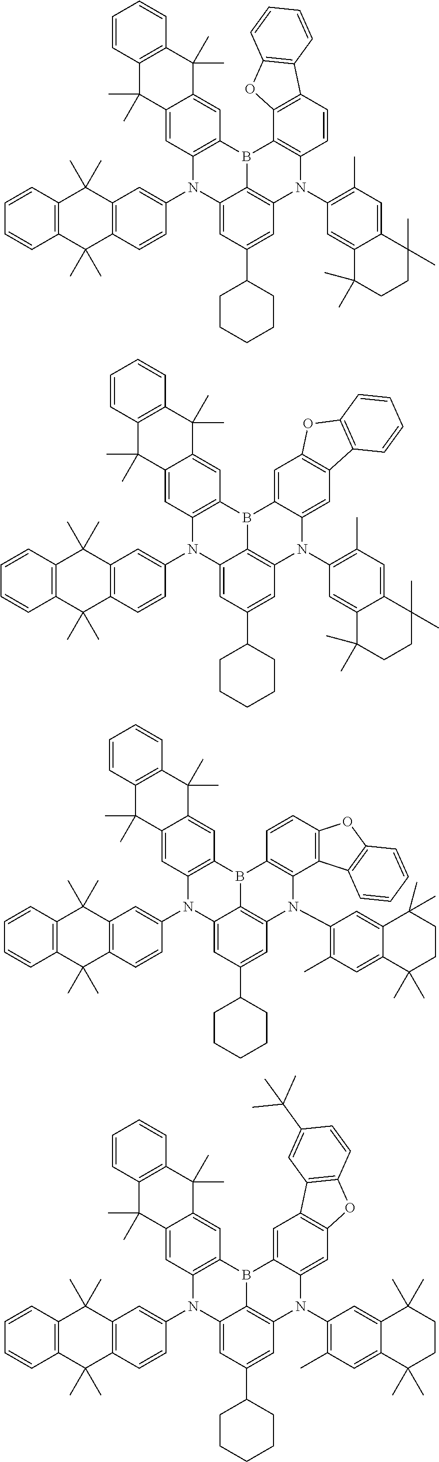

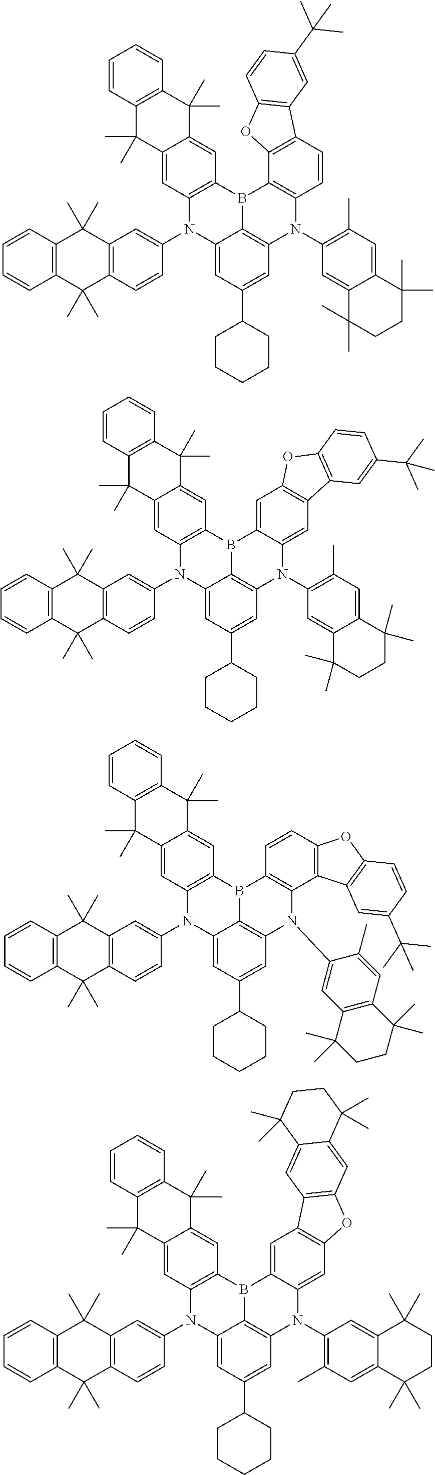

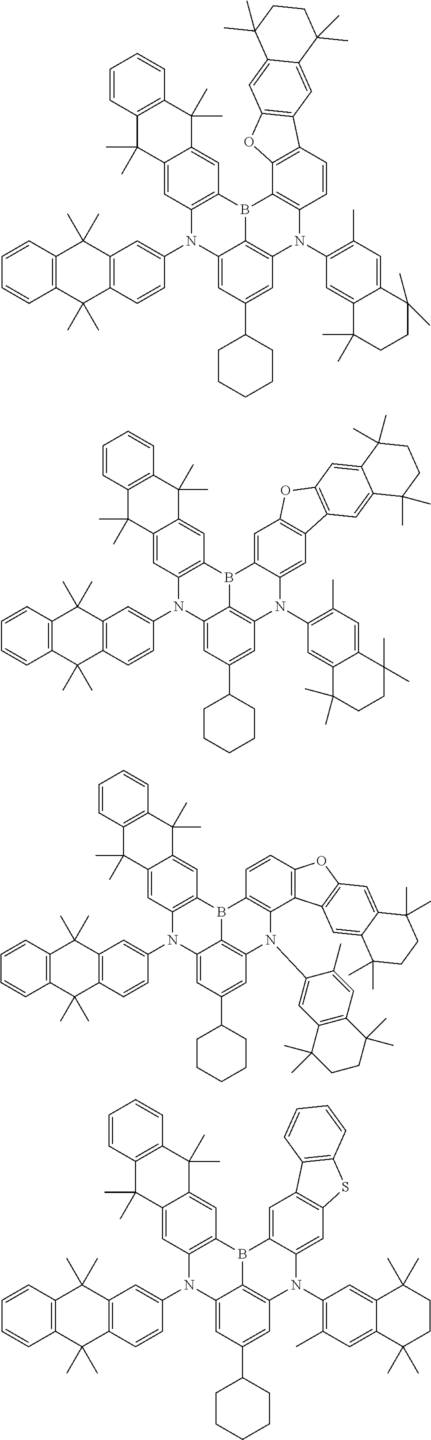

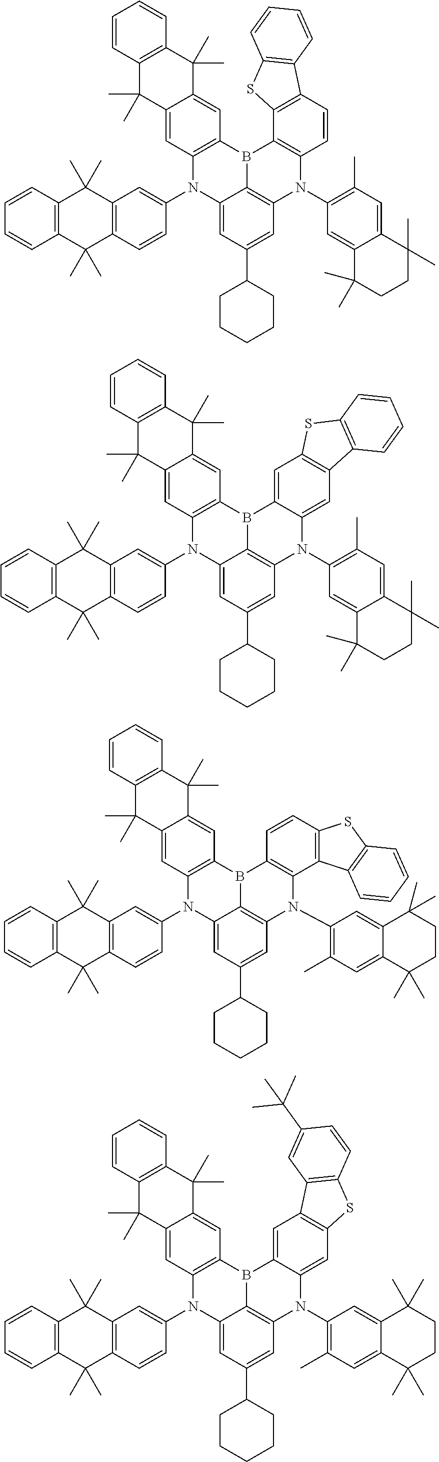

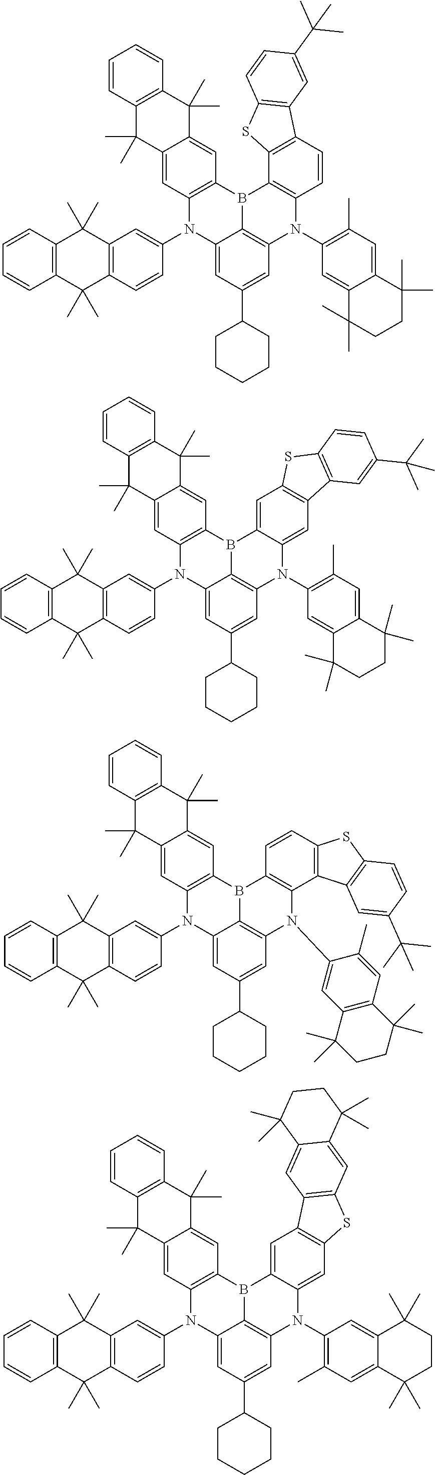

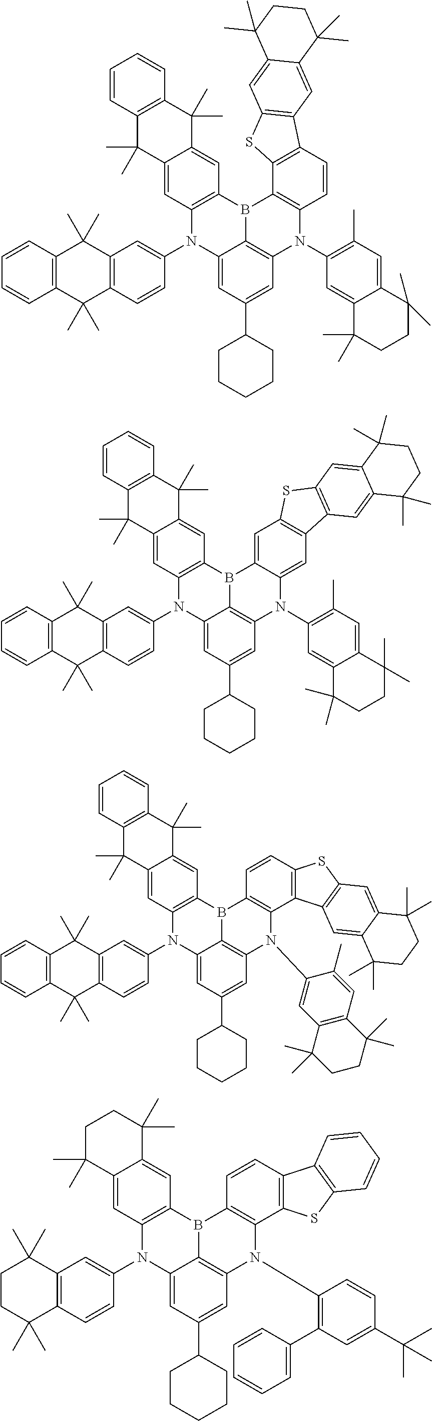

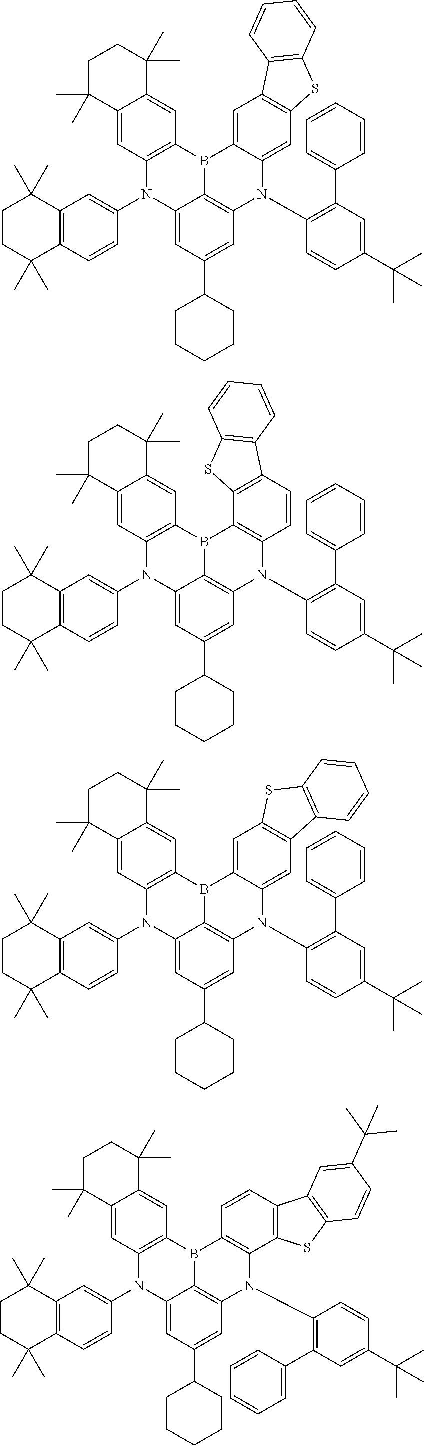

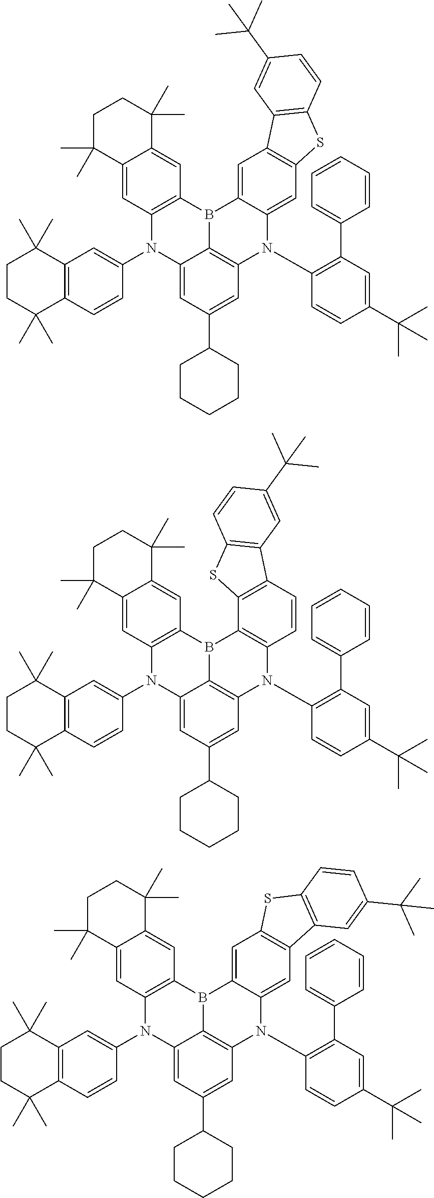

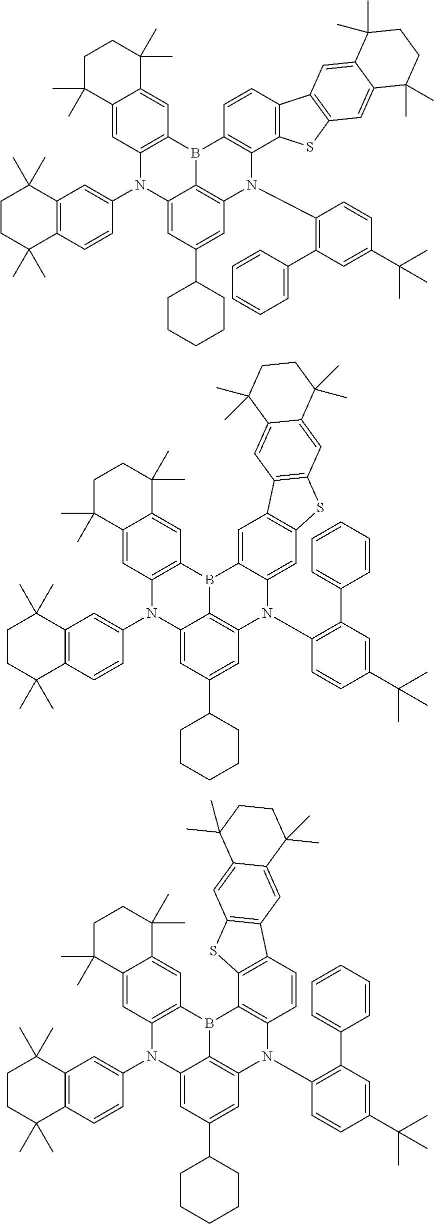

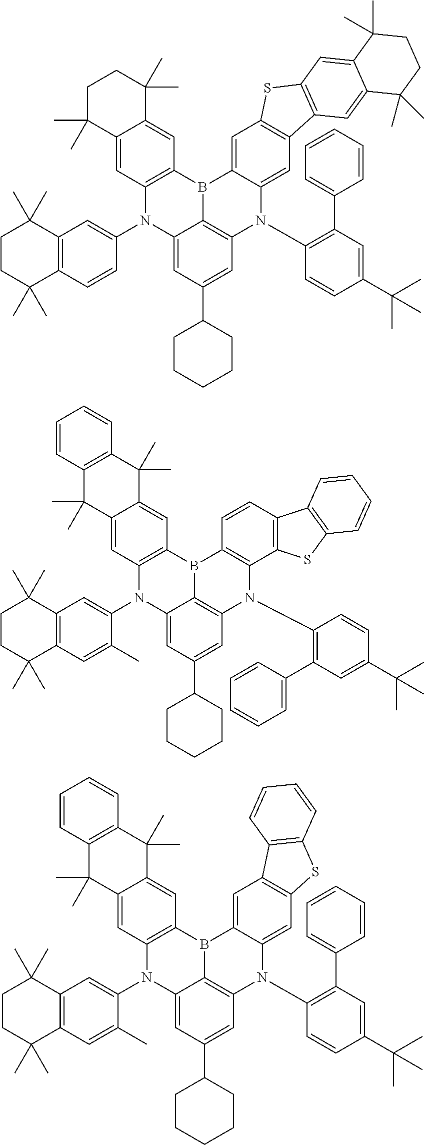 [SMILES: CC(C)(C)c1ccc(N2c3cc4c(cc3B3c5cc6c(cc5N(c5ccc7c(c5)C(C)(C)CCC7(C)C)c5cc(C7CCCCC7)cc2c53)C(C)(C)CCC6(C)C)sc2cc3c(cc24)C(C)(C)CCC3(C)C)c(-c2ccccc2)c1 ; Cc1cc2c(cc1N1c3cc4c(cc3B3c5ccc6c(sc7ccccc76)c5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)sc1ccccc16)C(C)(C)c1ccccc1C4(C)C)C(C)(C)CCC2(C)C]

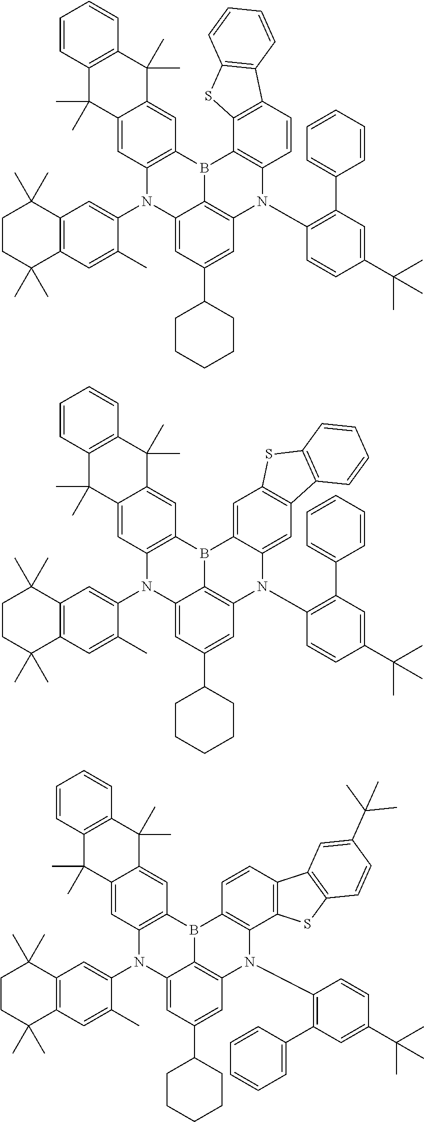 [SMILES: Cc1cc2c(cc1N1c3cc4c(cc3B3c5c1cc(C1CCCCC1)cc5N(c1ccc(C(C)(C)C)cc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(C6CCCCC6)cc1c53)C(C)(C)c1ccccc1C4(C)C)C(C)(C)CCC2(C)C]

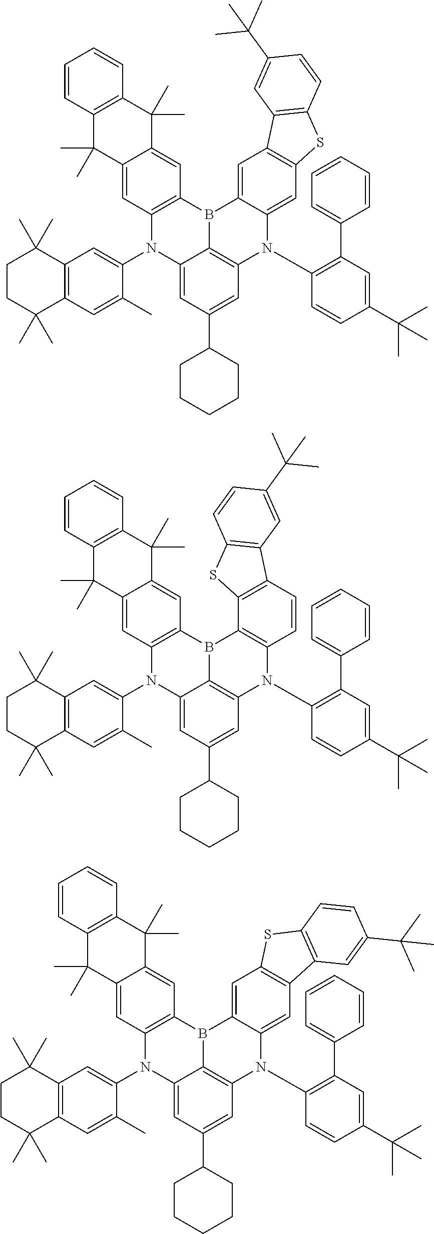 [SMILES: Cc1cc2c(cc1N1c3cc4c(cc3B3c5cc6c(cc5N(c5ccc(C(C)(C)C)cc5-c5ccccc5)c5cc(C7CCCCC7)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(C6CCCCC6)cc1c53)C(C)(C)c1ccccc1C4(C)C)C(C)(C)CCC2(C)C]

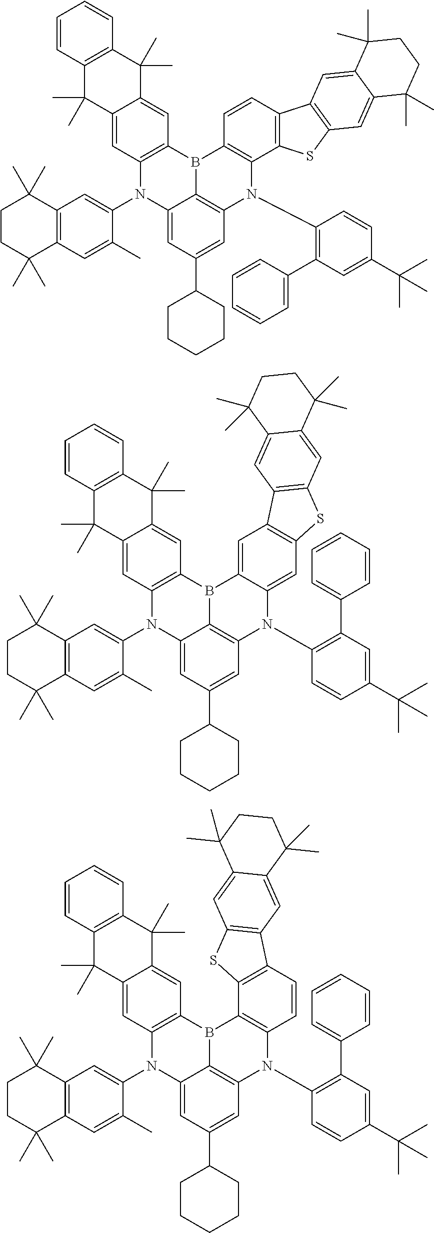

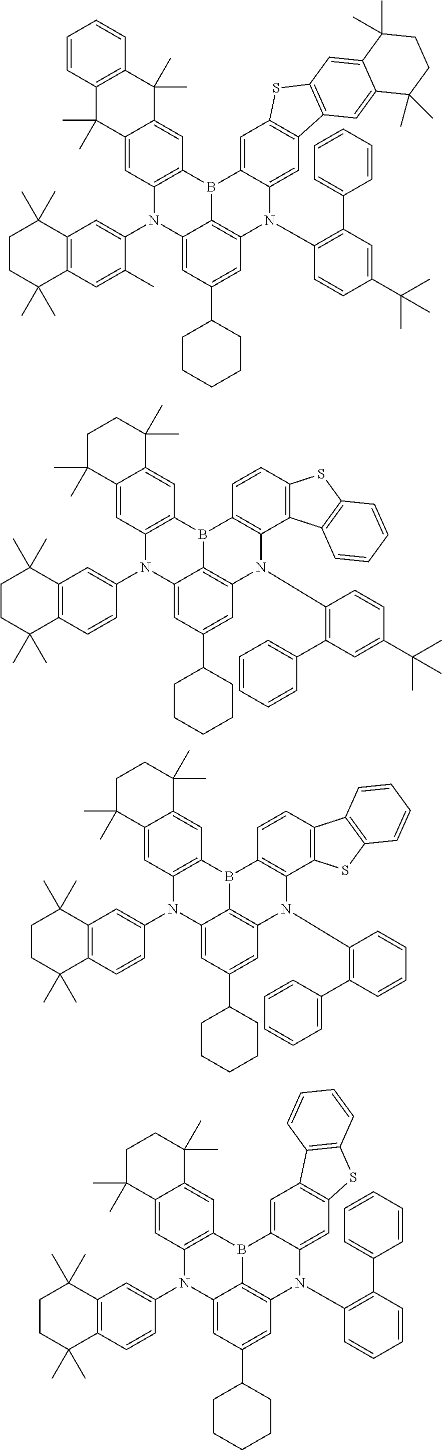

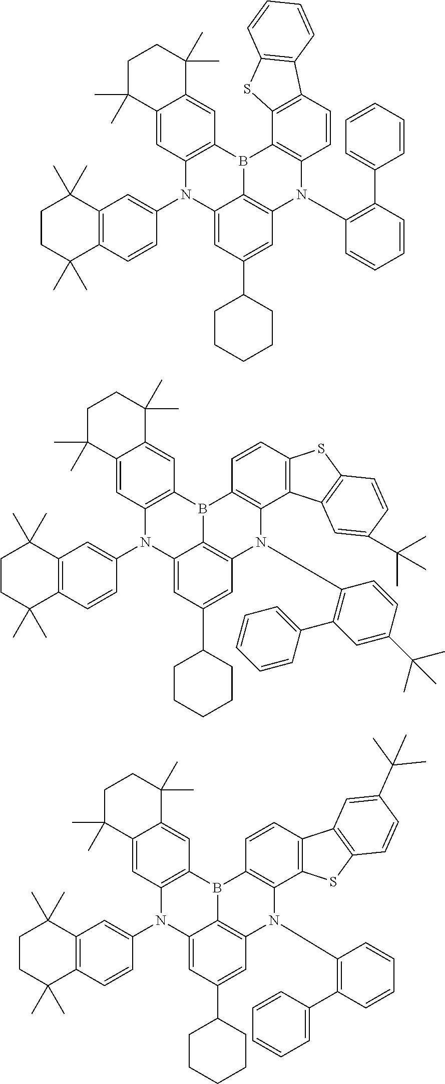

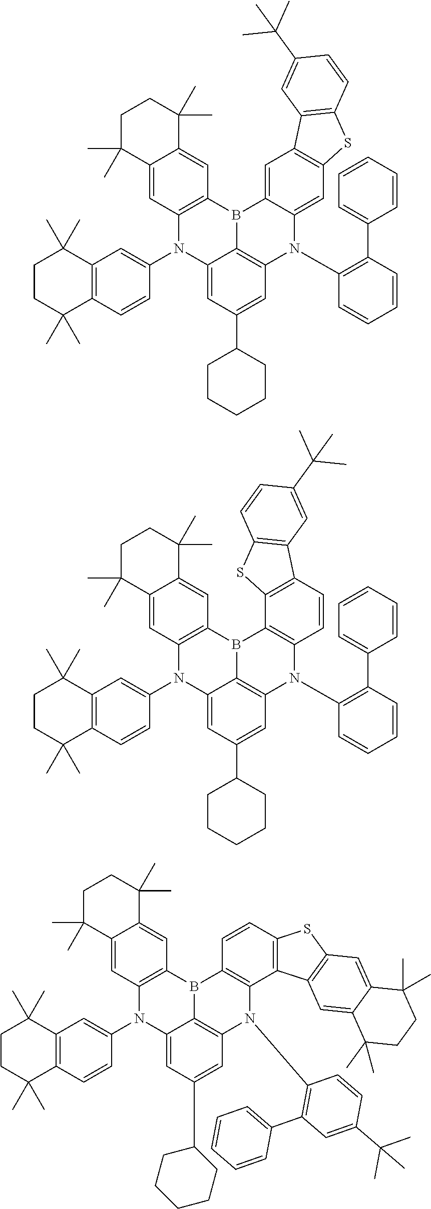 [SMILES: CC(C)(C)c1ccc2sc3cc4c(cc3c2c1)B1c2cc3c(cc2N(c2ccc5c(c2)C(C)(C)CCC5(C)C)c2cc(C5CCCCC5)cc(c21)N4c1ccccc1-c1ccccc1)C(C)(C)CCC3(C)C ; CC(C)(C)c1ccc2sc3c4c(ccc3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4sc5cc6c(cc5c4c32)C(C)(C)CCC6(C)C)c(-c2ccccc2)c1]

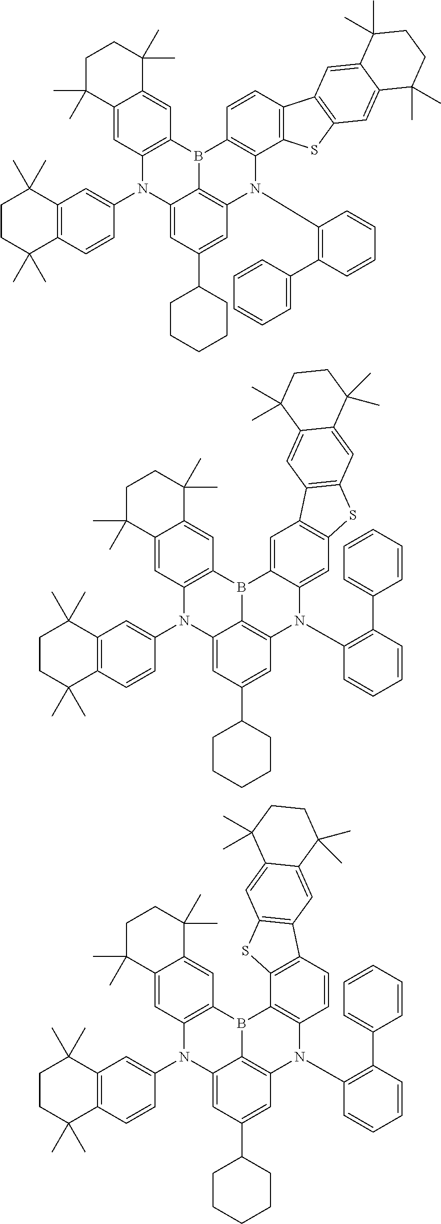

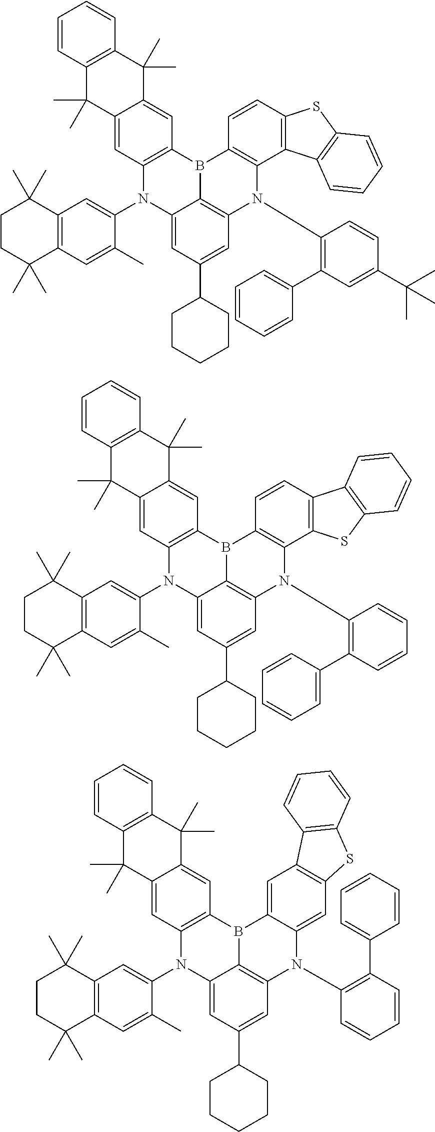 [SMILES: Cc1cc2c(cc1N1c3cc4c(cc3B3c5ccc6sc7ccccc7c6c5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C7CCCCC7)cc1c53)sc1ccccc16)C(C)(C)c1ccccc1C4(C)C)C(C)(C)CCC2(C)C]

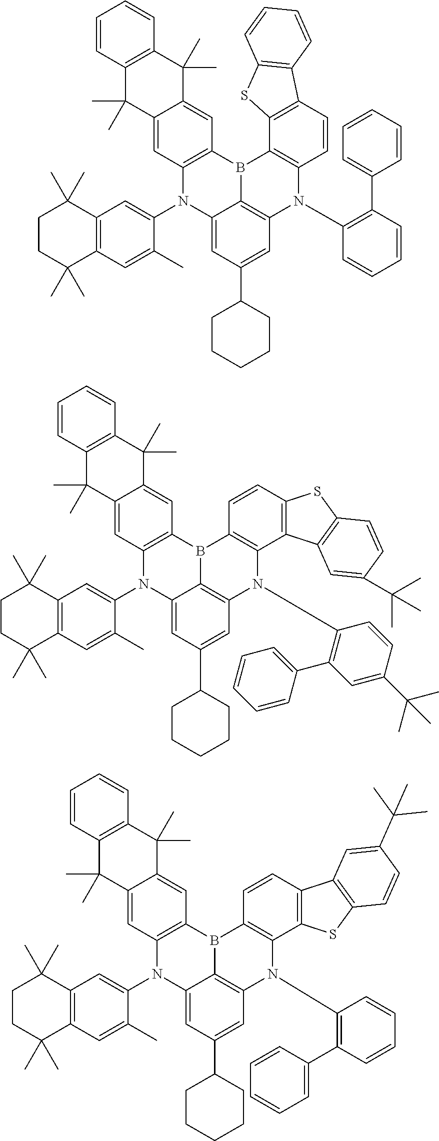 [SMILES: Cc1cc2c(cc1N1c3cc4c(cc3B3c5c1cc(C1CCCCC1)cc5N(c1ccccc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(C6CCCCC6)cc1c53)C(C)(C)c1ccccc1C4(C)C)C(C)(C)CCC2(C)C]

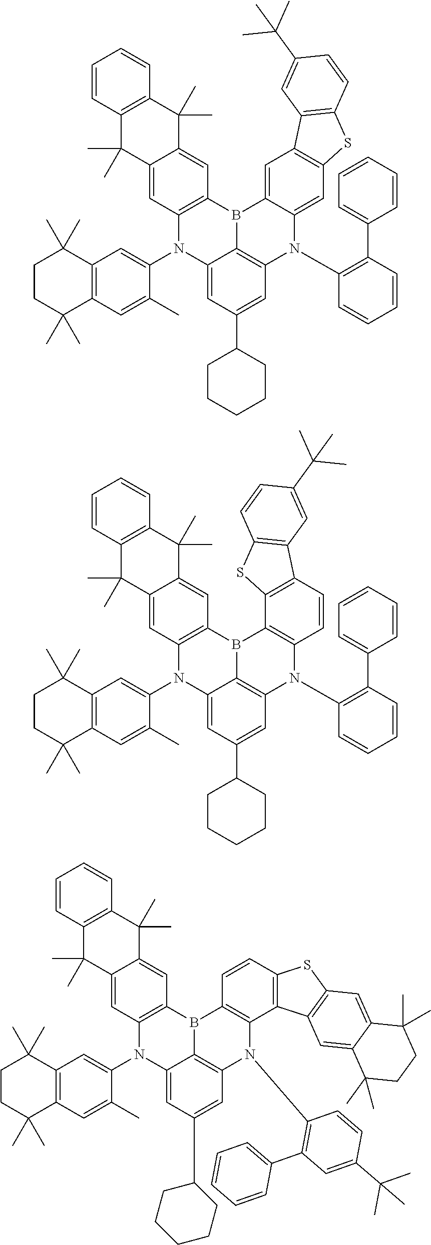 [SMILES: Cc1cc2c(cc1N1c3cc4c(cc3B3c5cc6c(cc5N(c5ccccc5-c5ccccc5)c5cc(C7CCCCC7)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccccc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(C6CCCCC6)cc1c53)C(C)(C)CCC8(C)C)C(C)(C)c1ccccc1C4(C)C)C(C)(C)CCC2(C)C]

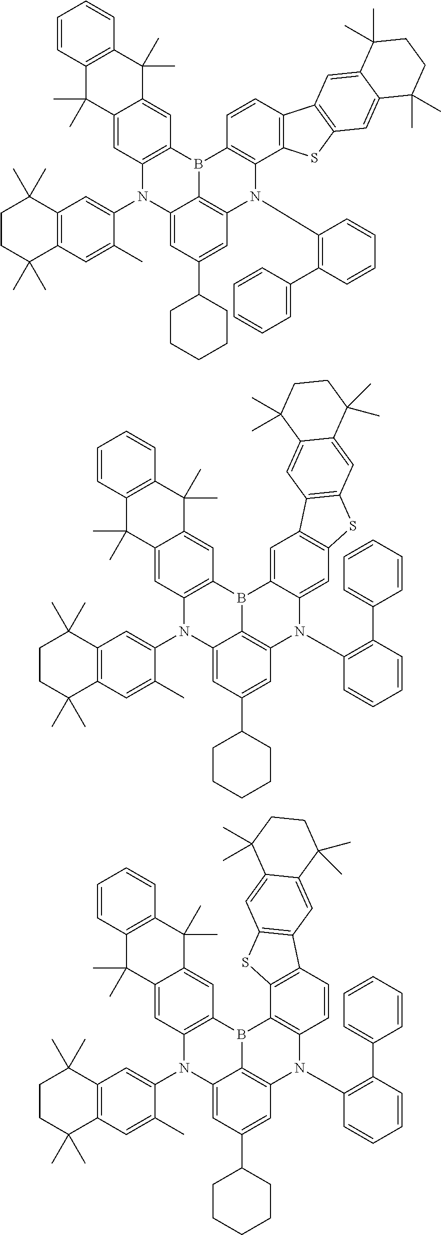

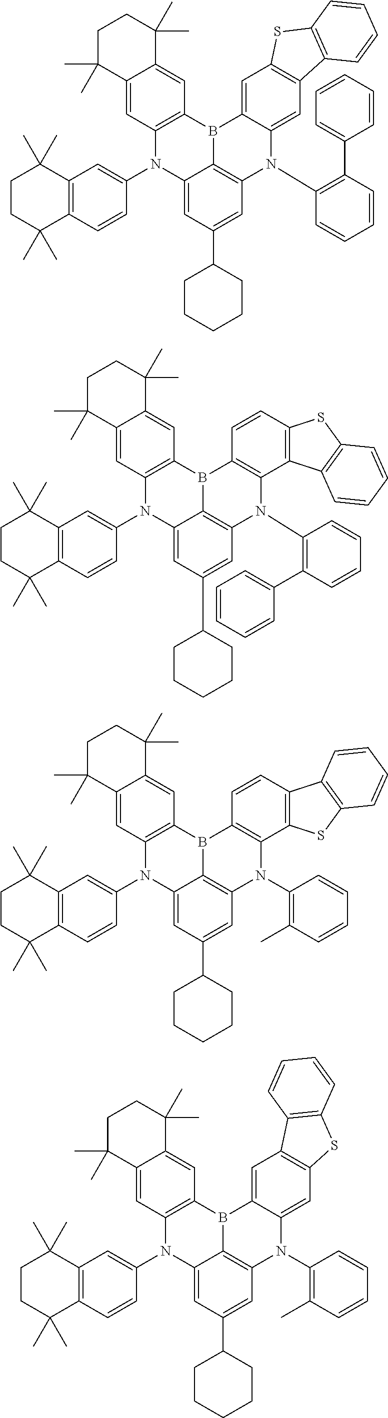

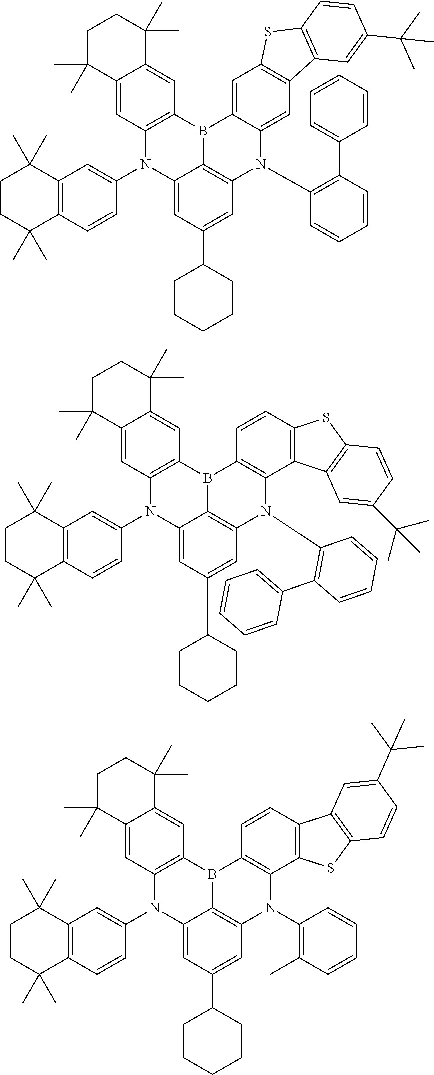

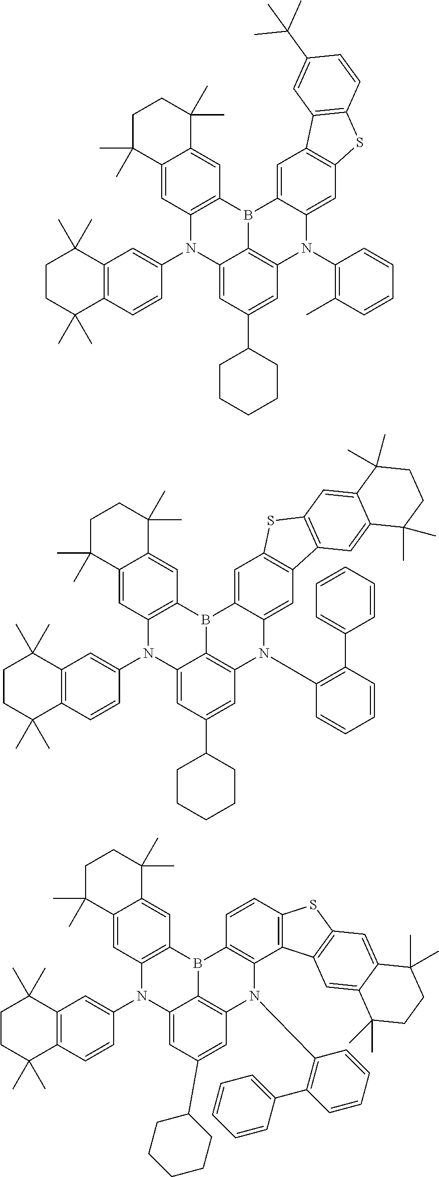

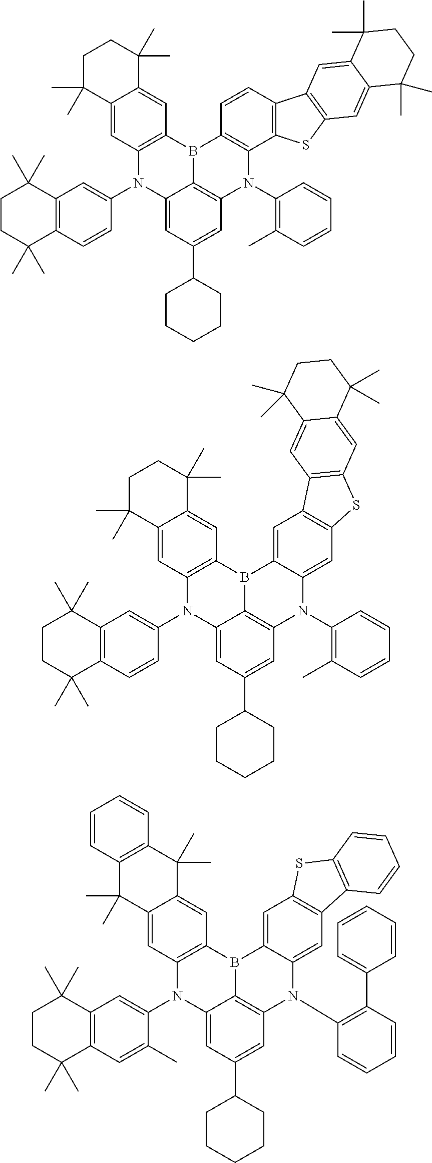 [SMILES: Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(sc4cc5c(cc43)C(C)(C)CCC5(C)C)c21 ; Cc1ccccc1N1c2cc3sc4cc5c(cc4c3cc2B2c3cc4c(cc3N(c3ccc6c(c3)C(C)(C)CCC6(C)C)c3cc(C6CCCCC6)cc1c32)C(C)(C)CCC4(C)C)C(C)(C)CCC5(C)C ; Cc1cc2c(cc1N1c3cc4c(cc3B3c5cc6sc7ccccc7c6cc5N(c5ccccc5-c5ccccc5)c5cc(C6CCCCC6)cc1c53)C(C)(C)c1ccccc1C4(C)C)C(C)(C)CCC2(C)C]

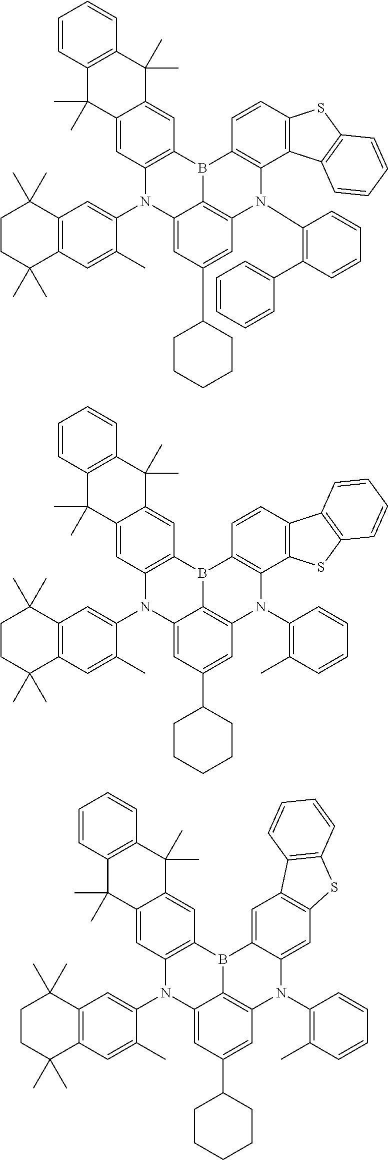 [SMILES: Cc1cc2c(cc1N1c3cc4c(cc3B3c5ccc6sc7ccccc7c6c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5C)c5cc(C6CCCCC6)cc1c53)C(C)(C)c1ccccc1C4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(C5CCCCC5)cc1c32)C(C)(C)c1ccccc1C4(C)C]

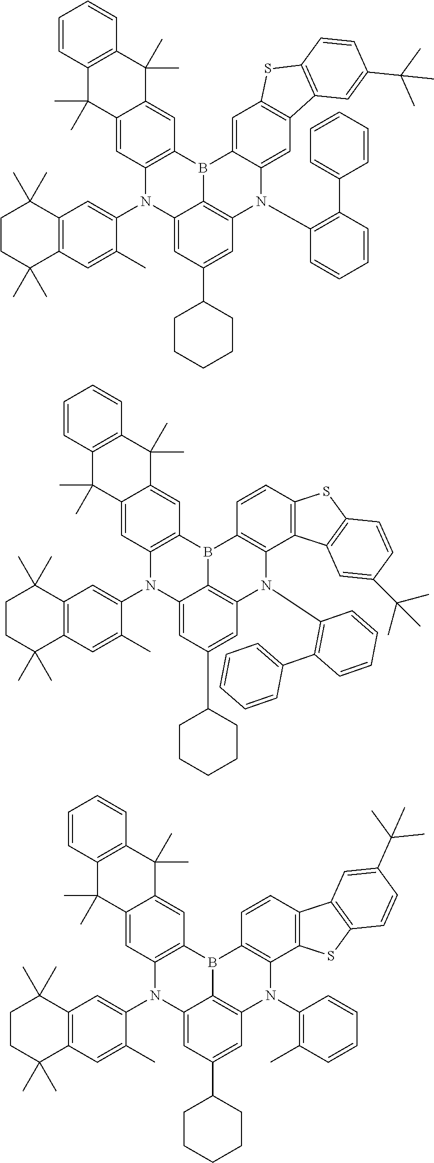 [SMILES: Cc1cc2c(cc1N1c3cc4c(cc3B3c5cc6sc7ccc(C(C)(C)C)cc7c6cc5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(C6CCCCC6)cc1c53)C(C)(C)c1ccccc1C4(C)C)C(C)(C)CCC2(C)C]

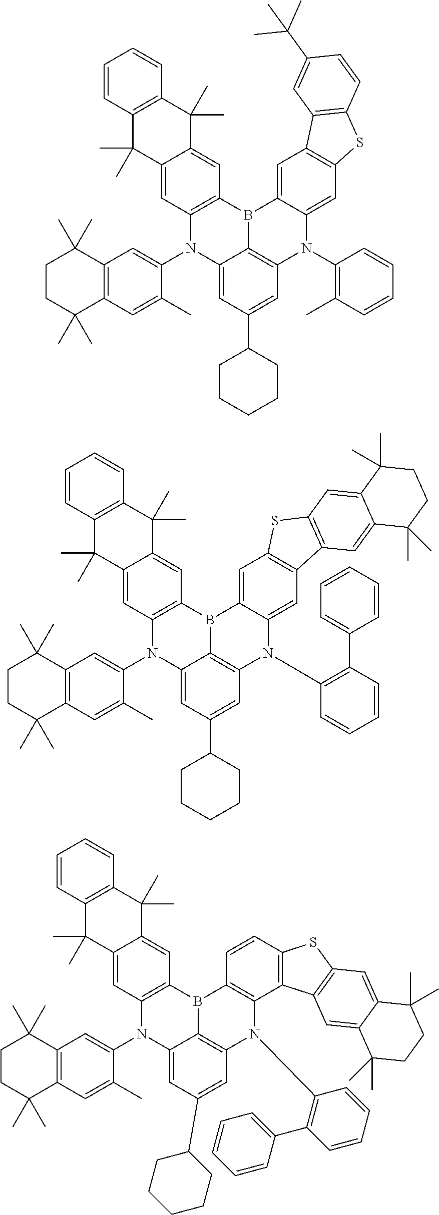 [SMILES: Cc1ccccc1N1c2cc3sc4ccc(C(C)(C)C)cc4c3cc2B2c3cc4c(cc3N(c3cc5c(cc3C)C(C)(C)CCC5(C)C)c3cc(C5CCCCC5)cc1c32)C(C)(C)c1ccccc1C4(C)C ; Cc1cc2c(cc1N1c3cc4c(cc3B3c5cc6sc7cc8c(cc7c6cc5N(c5ccccc5-c5ccccc5)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(C6CCCCC6)cc1c53)C(C)(C)CCC8(C)C)C(C)(C)c1ccccc1C4(C)C)C(C)(C)CCC2(C)C]

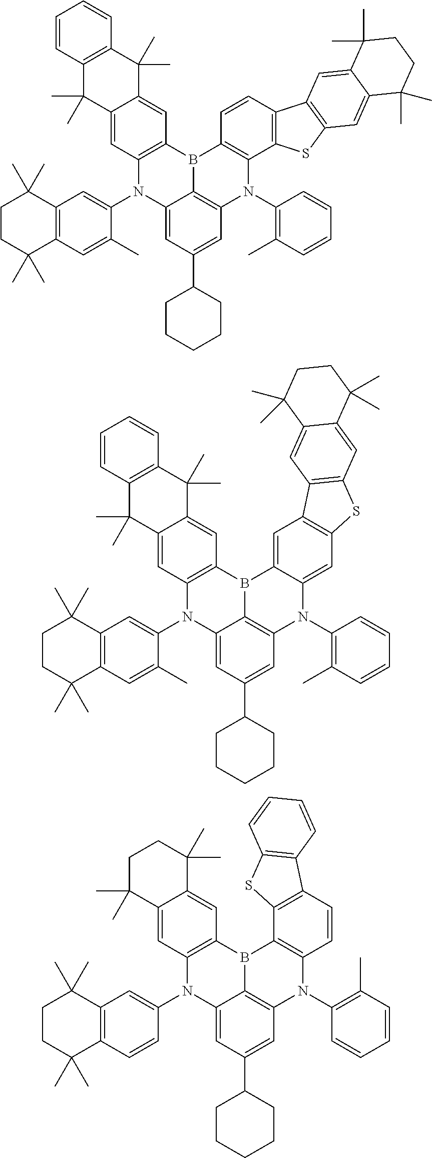

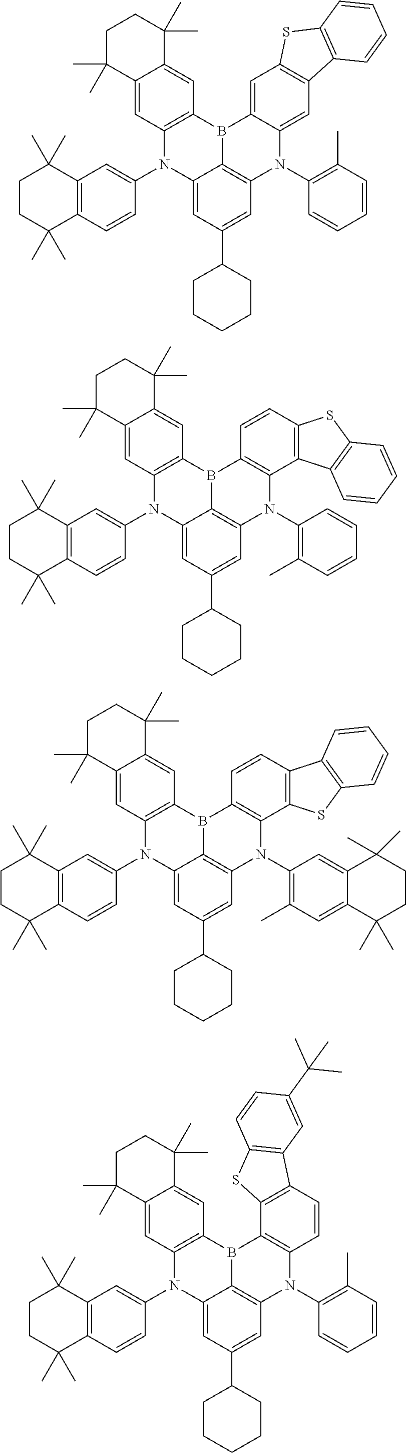

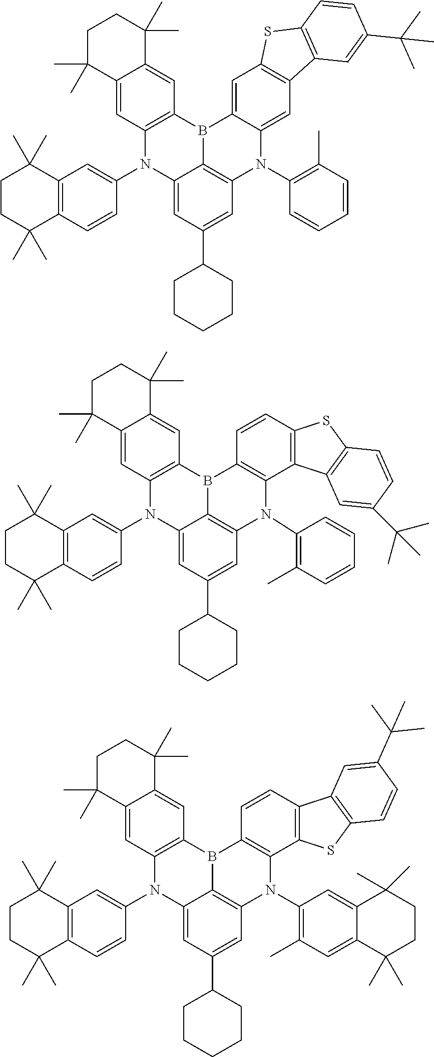

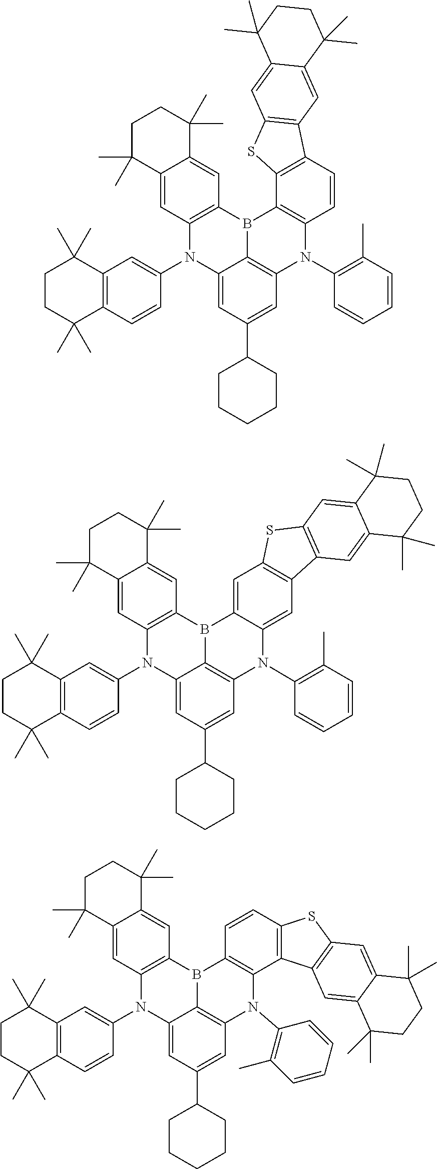

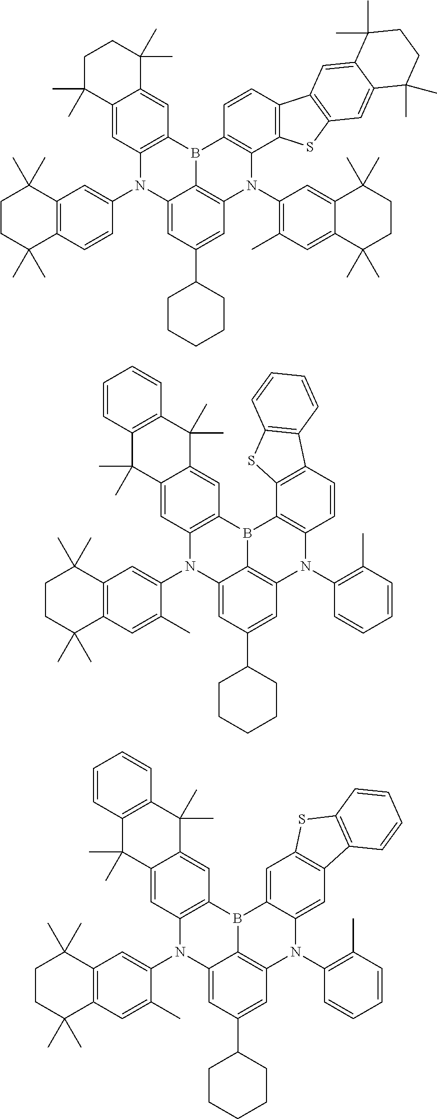 [SMILES: Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(sc5cc6c(cc54)C(C)(C)CCC6(C)C)c31)C(C)(C)CCC2(C)C ; Cc1cc2c(cc1N1c3cc4c(cc3B3c5c1cc(C1CCCCC1)cc5N(c1ccccc1C)c1ccc5c(sc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)sc1ccccc13]

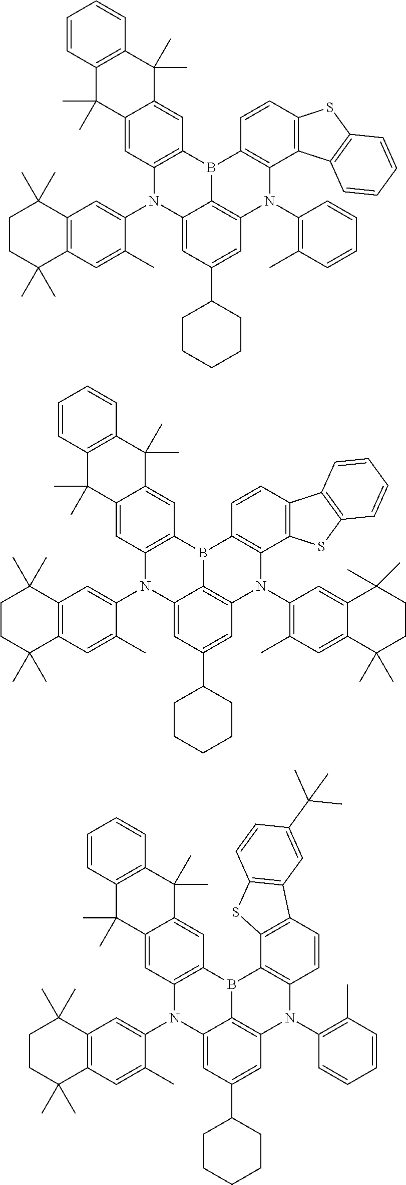 [SMILES: Cc1cc2c(cc1N1c3cc4c(cc3B3c5ccc6sc7ccccc7c6c5N(c5ccccc5C)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(C6CCCCC6)cc1c53)C(C)(C)c1ccccc1C4(C)C)C(C)(C)CCC2(C)C ; Cc1cc2c(cc1N1c3cc4c(cc3B3c5c1cc(C1CCCCC1)cc5N(c1ccccc1C)c1ccc5c(sc6ccc(C(C)(C)C)cc65)c13)C(C)(C)c1ccccc1C4(C)C)C(C)(C)CCC2(C)C]

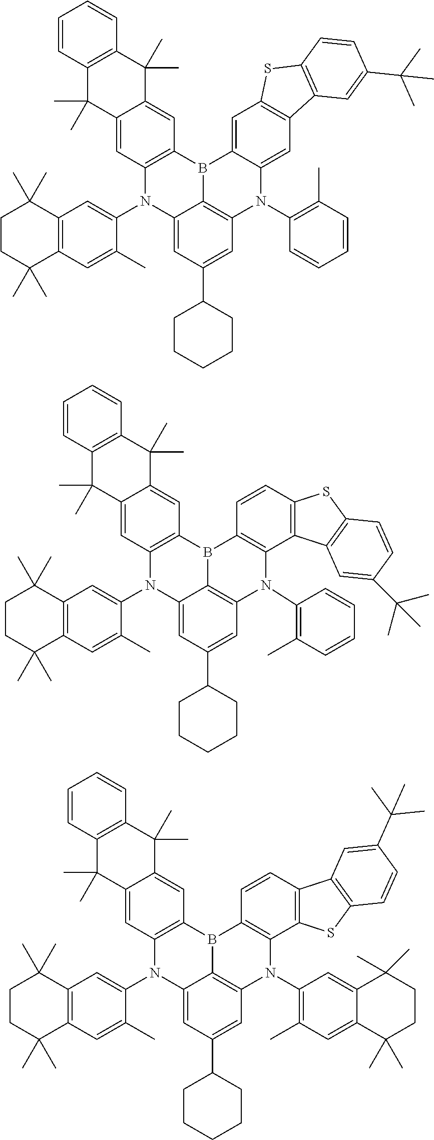 [SMILES: Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)sc1ccc(C(C)(C)C)cc13 ; Cc1cc2c(cc1N1c3cc4c(cc3B3c5ccc6sc7ccc(C(C)(C)C)cc7c6c5N(c5ccccc5C)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(C6CCCCC6)cc1c53)C(C)(C)c1ccccc1C4(C)C)C(C)(C)CCC2(C)C]

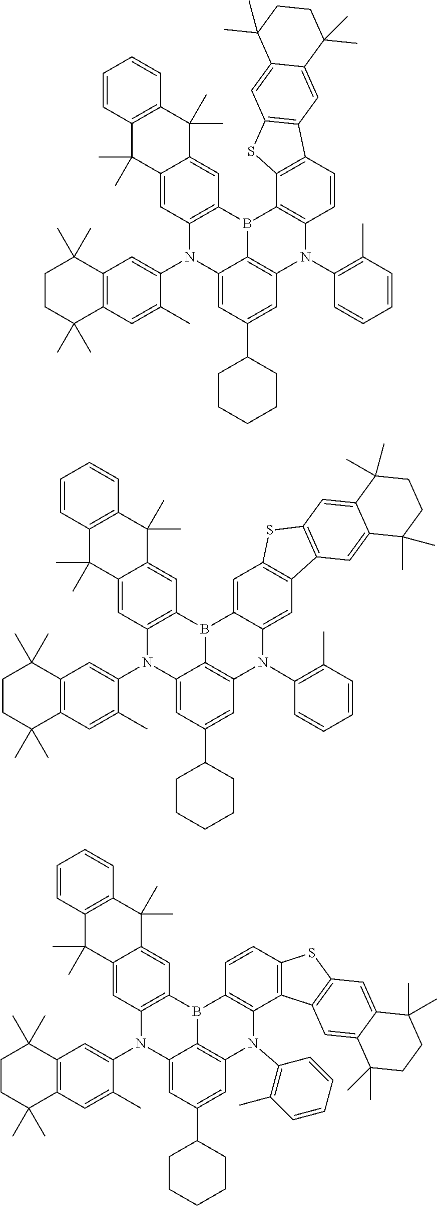 [SMILES: Cc1cc2c(cc1N1c3cc4c(cc3B3c5c1cc(C1CCCCC1)cc5N(c1ccccc1C)c1ccc5c(sc6cc7c(cc65)C(C)(C)CCC7(C)C)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(C6CCCCC6)cc1c53)C(C)(C)CCC8(C)C)C(C)(C)c1ccccc1C4(C)C)C(C)(C)CCC2(C)C]

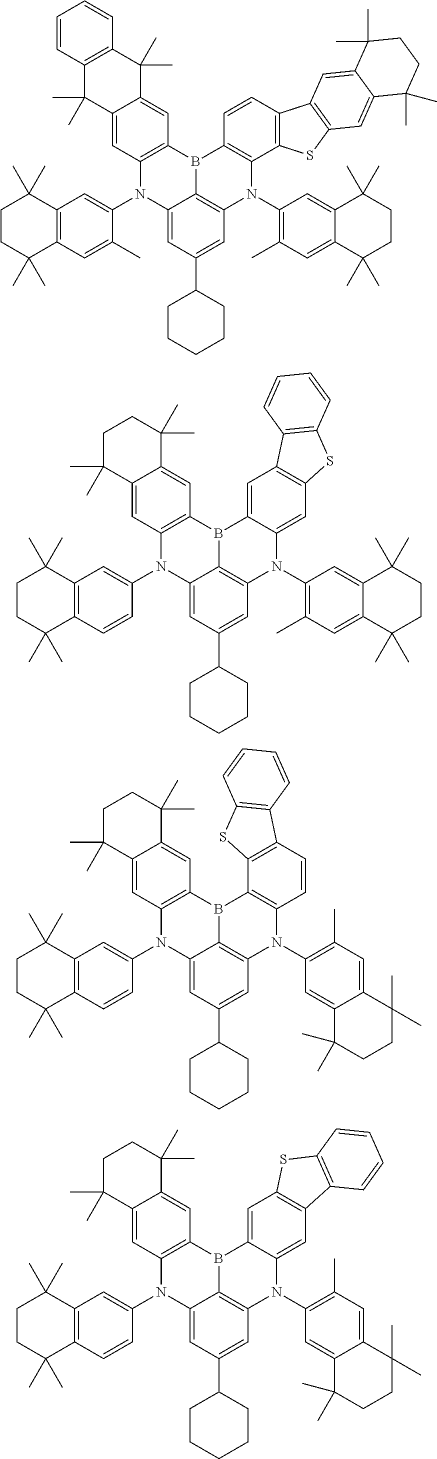

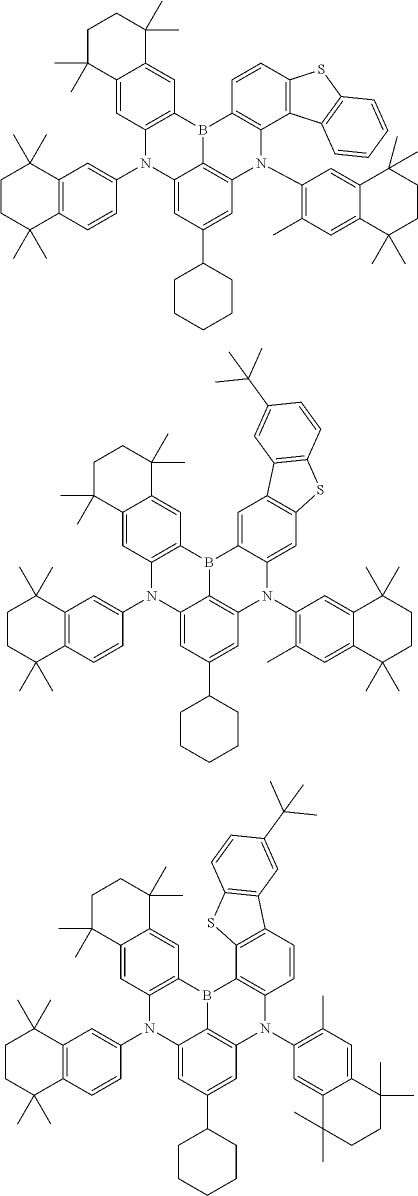

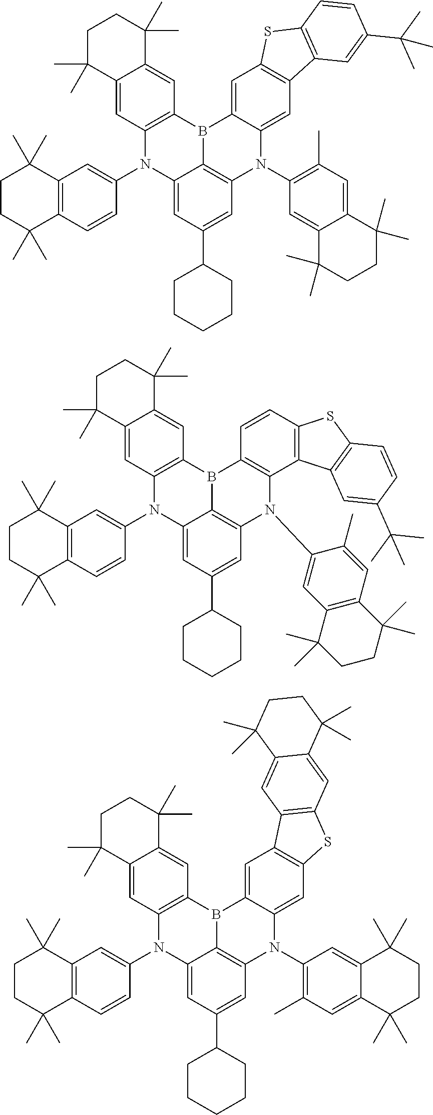

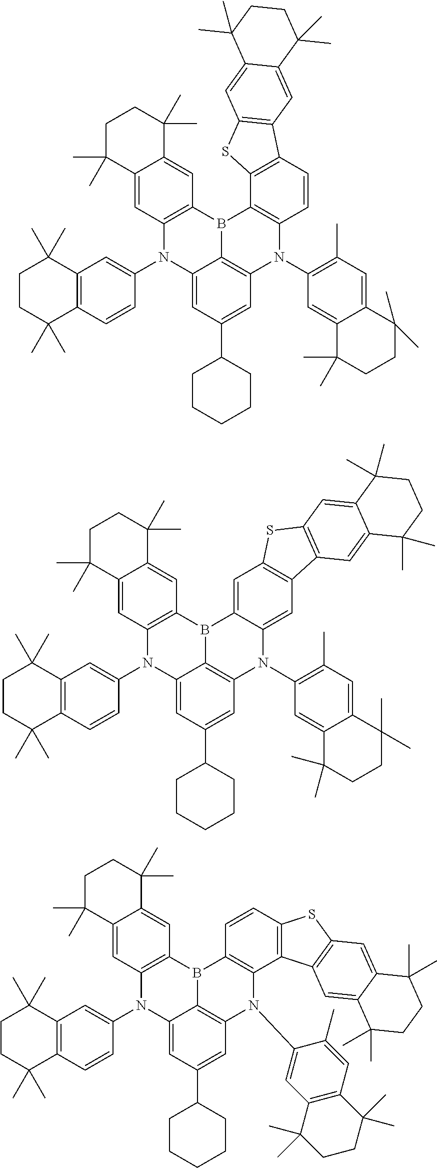

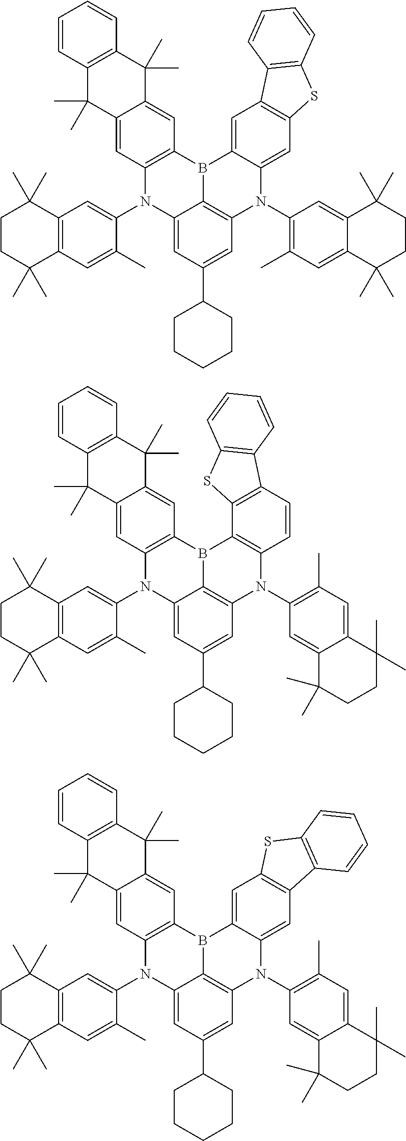

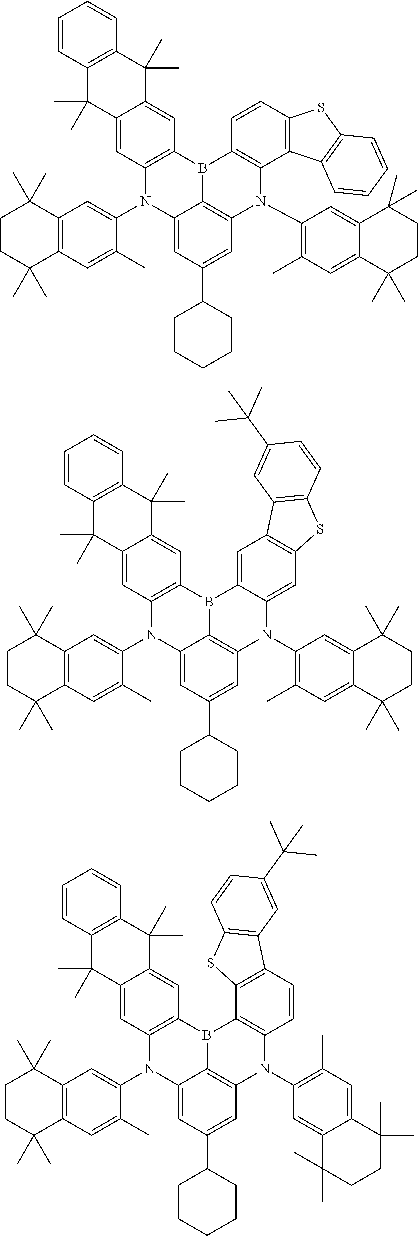

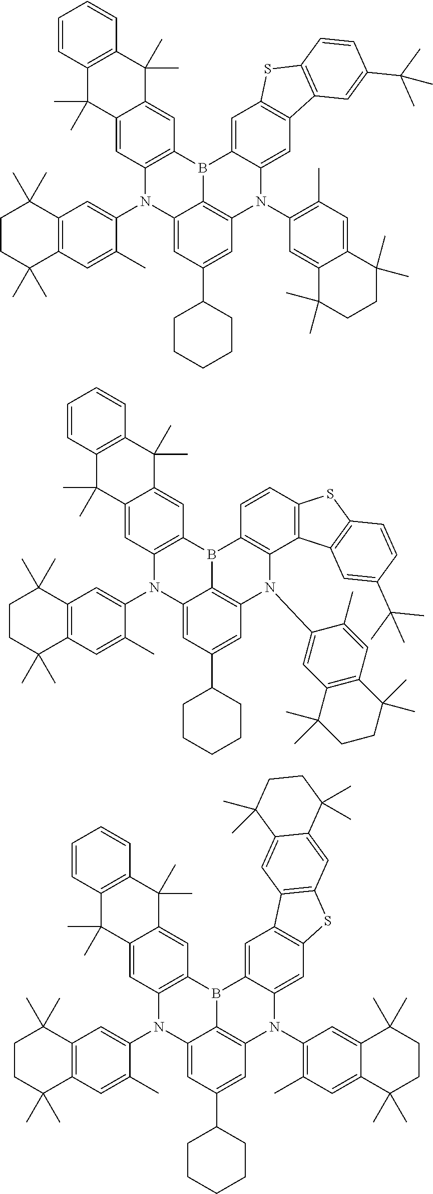

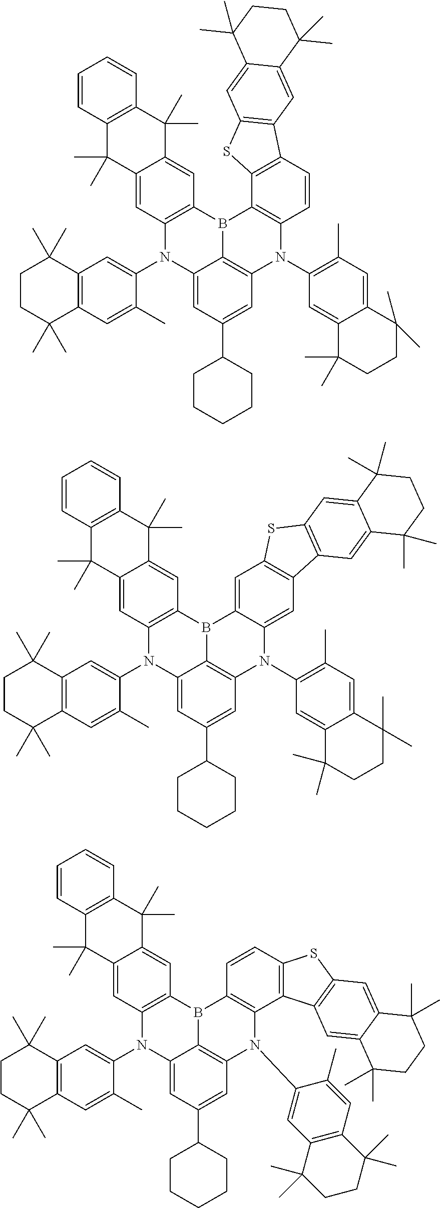 [SMILES: Cc1cc2c(cc1N1c3cc4c(cc3B3c5c1cc(C1CCCCC1)cc5N(c1cc5c(cc1C)C(C)(C)CCC5(C)C)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5cc6c(cc5C)C(C)(C)CCC6(C)C)c5cc(C6CCCCC6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5cc6c(cc5C)C(C)(C)CCC6(C)C)c5cc(C6CCCCC6)cc1c53)C(C)(C)CCC8(C)C)C(C)(C)c1ccccc1C4(C)C)C(C)(C)CCC2(C)C]

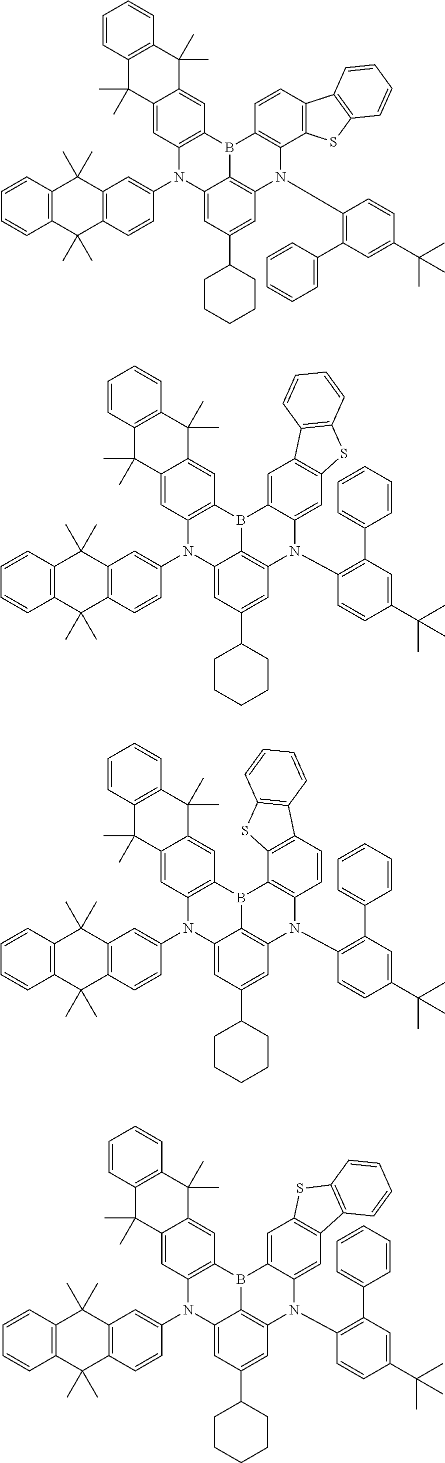

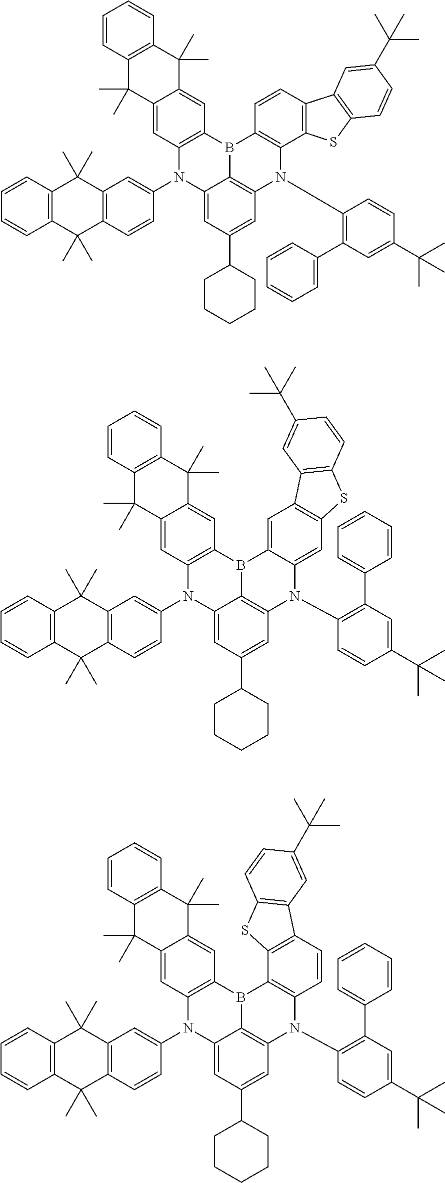 [SMILES: CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(sc5ccc(C(C)(C)C)cc54)c32)c(-c2ccccc2)c1 ; CC(C)(C)c1ccc(N2c3cc4sc5ccc(C(C)(C)C)cc5c4cc3B3c4cc5c(cc4N(c4ccc6c(c4)C(C)(C)c4ccccc4C6(C)C)c4cc(C6CCCCC6)cc2c43)C(C)(C)c2ccccc2C5(C)C)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3c2ccc2c3sc3ccc(C(C)(C)C)cc32)c(-c2ccccc2)c1]

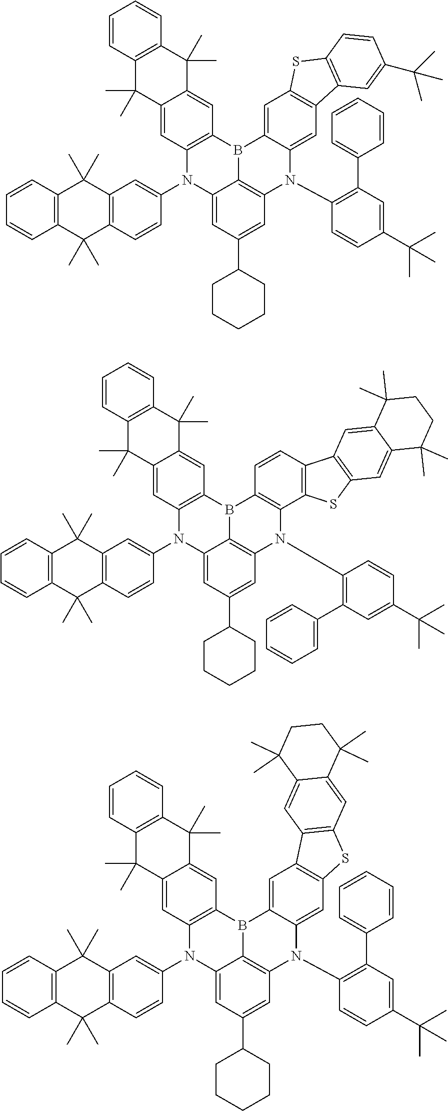 [SMILES: CC(C)(C)c1ccc(N2c3cc4c(cc3B3c5cc6c(cc5N(c5ccc7c(c5)C(C)(C)c5ccccc5C7(C)C)c5cc(C7CCCCC7)cc2c53)C(C)(C)c2ccccc2C6(C)C)sc2ccc(C(C)(C)C)cc24)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(sc5cc6c(cc54)C(C)(C)CCC6(C)C)c32)c(-c2ccccc2)c1 ; CC(C)(C)c1ccc(N2c3cc4sc5cc6c(cc5c4cc3B3c4cc5c(cc4N(c4ccc7c(c4)C(C)(C)c4ccccc4C7(C)C)c4cc(C7CCCCC7)cc2c43)C(C)(C)c2ccccc2C5(C)C)C(C)(C)CCC6(C)C)c(-c2ccccc2)c1]

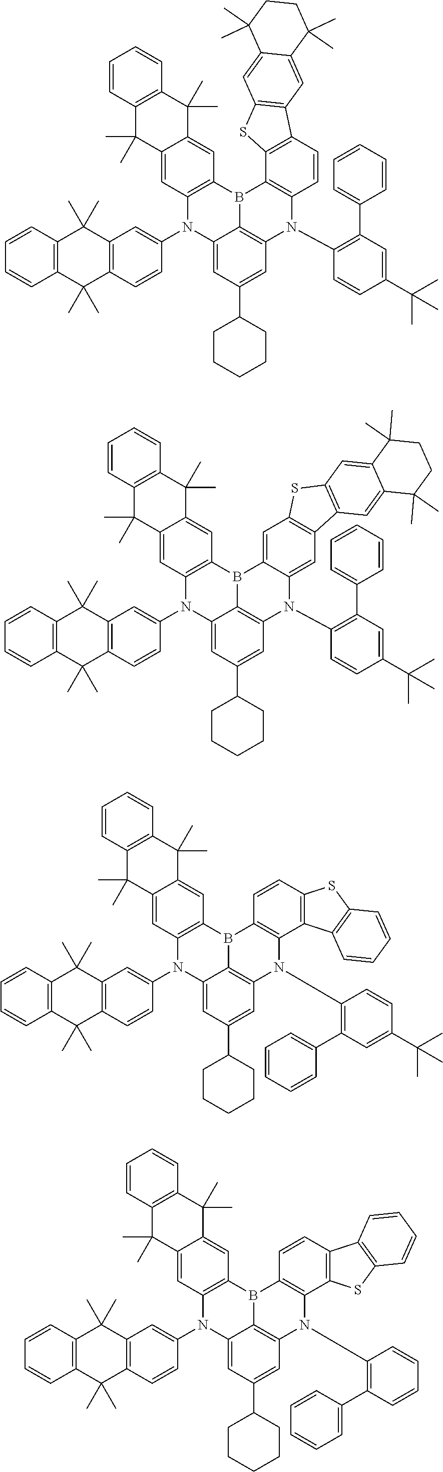

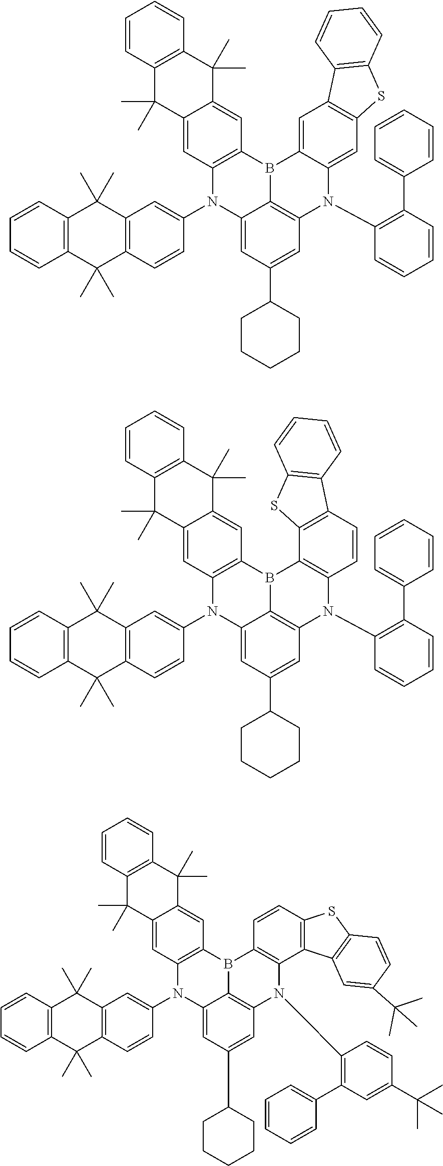 [SMILES: CC1(C)c2ccccc2C(C)(C)c2cc(N3c4cc5c(cc4B4c6cc7c(cc6N(c6ccccc6-c6ccccc6)c6cc(C8CCCCC8)cc3c64)sc3ccccc37)C(C)(C)c3ccccc3C5(C)C)ccc21 ; CC1(C)c2ccccc2C(C)(C)c2cc(N3c4cc5c(cc4B4c6c3cc(C3CCCCC3)cc6N(c3ccccc3-c3ccccc3)c3ccc6c(sc7ccccc76)c34)C(C)(C)c3ccccc3C5(C)C)ccc21 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4sc5ccc(C(C)(C)C)cc5c4c32)c(-c2ccccc2)c1]

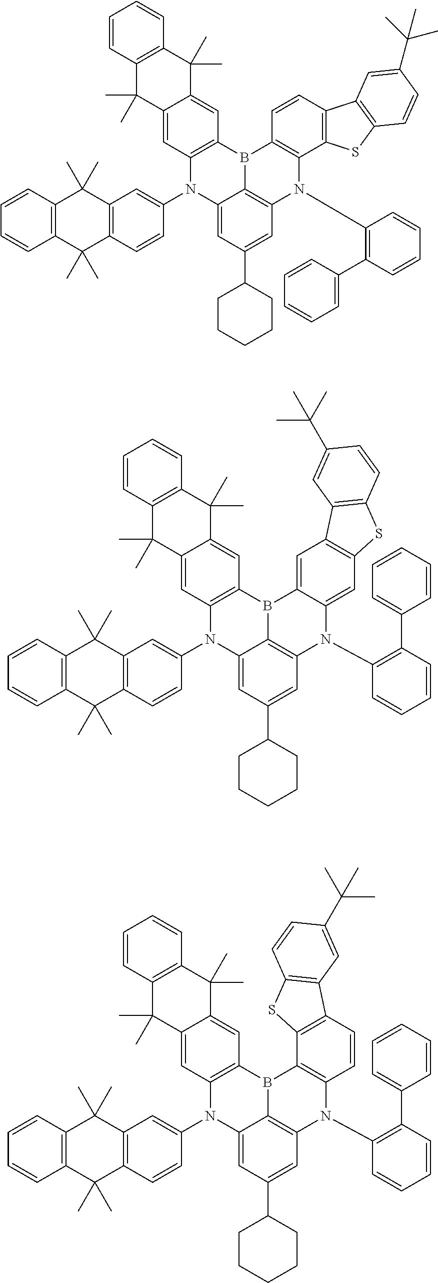 [SMILES: CC(C)(C)c1ccc2sc3c4c(ccc3c2c1)B1c2cc3c(cc2N(c2ccc5c(c2)C(C)(C)c2ccccc2C5(C)C)c2cc(C5CCCCC5)cc(c21)N4c1ccccc1-c1ccccc1)C(C)(C)c1ccccc1C3(C)C ; CC(C)(C)c1ccc2sc3cc4c(cc3c2c1)B1c2cc3c(cc2N(c2ccc5c(c2)C(C)(C)c2ccccc2C5(C)C)c2cc(C5CCCCC5)cc(c21)N4c1ccccc1-c1ccccc1)C(C)(C)c1ccccc1C3(C)C ; CC(C)(C)c1ccc2sc3c4c(ccc3c2c1)N(c1ccccc1-c1ccccc1)c1cc(C2CCCCC2)cc2c1B4c1cc3c(cc1N2c1ccc2c(c1)C(C)(C)c1ccccc1C2(C)C)C(C)(C)c1ccccc1C3(C)C]

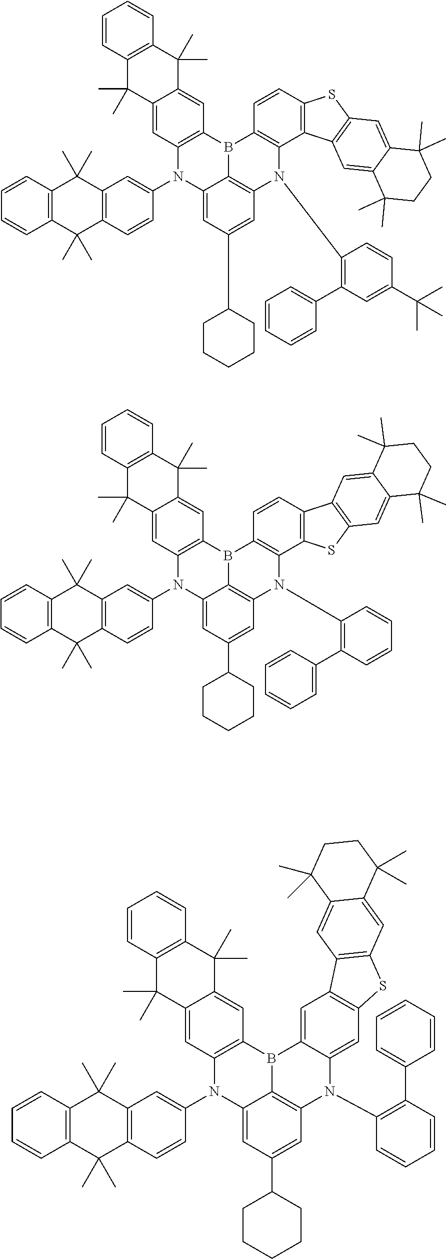 [SMILES: CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4sc5cc6c(cc5c4c32)C(C)(C)CCC6(C)C)c(-c2ccccc2)c1 ; CC1(C)CCC(C)(C)c2cc3c(cc21)sc1c2c(ccc13)B1c3cc4c(cc3N(c3ccc5c(c3)C(C)(C)c3ccccc3C5(C)C)c3cc(C5CCCCC5)cc(c31)N2c1ccccc1-c1ccccc1)C(C)(C)c1ccccc1C4(C)C ; CC1(C)CCC(C)(C)c2cc3c(cc21)sc1cc2c(cc13)B1c3cc4c(cc3N(c3ccc5c(c3)C(C)(C)c3ccccc3C5(C)C)c3cc(C5CCCCC5)cc(c31)N2c1ccccc1-c1ccccc1)C(C)(C)c1ccccc1C4(C)C]

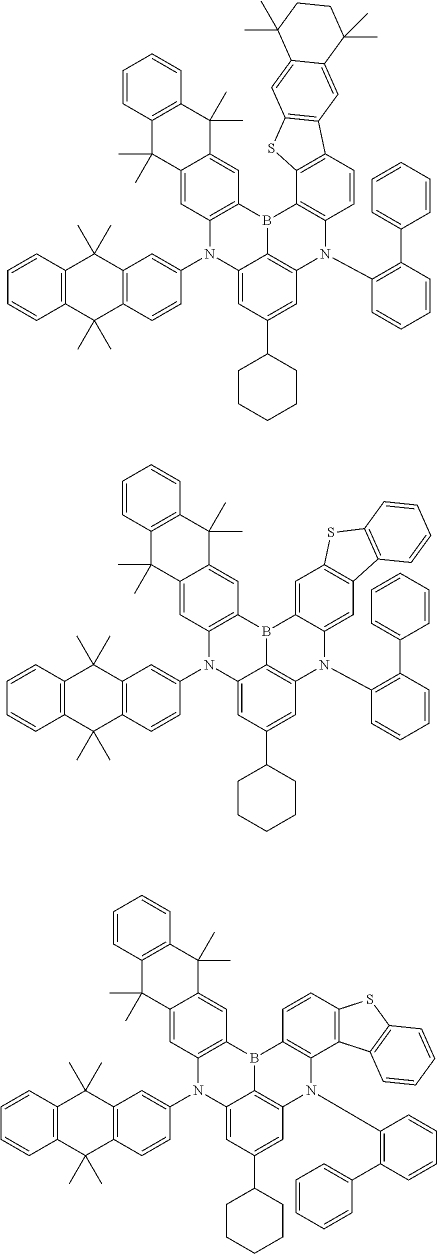 [SMILES: CC1(C)CCC(C)(C)c2cc3c(cc21)sc1c2c(ccc13)N(c1ccccc1-c1ccccc1)c1cc(C3CCCCC3)cc3c1B2c1cc2c(cc1N3c1ccc3c(c1)C(C)(C)c1ccccc1C3(C)C)C(C)(C)c1ccccc1C2(C)C ; CC1(C)c2ccccc2C(C)(C)c2cc(N3c4cc5c(cc4B4c6cc7sc8ccccc8c7cc6N(c6ccccc6-c6ccccc6)c6cc(C7CCCCC7)cc3c64)C(C)(C)c3ccccc3C5(C)C)ccc21 ; CC1(C)c2ccccc2C(C)(C)c2cc(N3c4cc5c(cc4B4c6ccc7sc8ccccc8c7c6N(c6ccccc6-c6ccccc6)c6cc(C7CCCCC7)cc3c64)C(C)(C)c3ccccc3C5(C)C)ccc21]

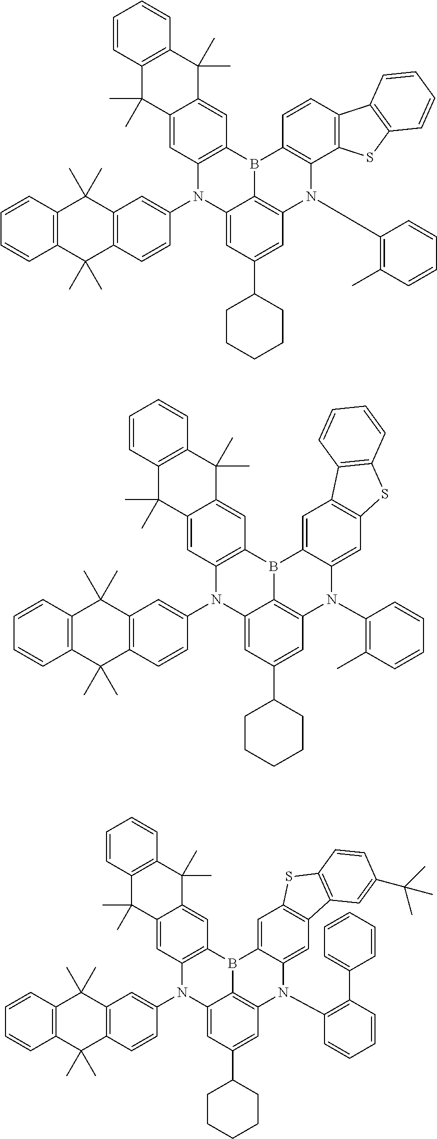 [SMILES: Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3c(sc4ccccc43)c21 ; Cc1ccccc1N1c2cc3sc4ccccc4c3cc2B2c3cc4c(cc3N(c3ccc5c(c3)C(C)(C)c3ccccc3C5(C)C)c3cc(C5CCCCC5)cc1c32)C(C)(C)c1ccccc1C4(C)C ; CC(C)(C)c1ccc2sc3cc4c(cc3c2c1)N(c1ccccc1-c1ccccc1)c1cc(C2CCCCC2)cc2c1B4c1cc3c(cc1N2c1ccc2c(c1)C(C)(C)c1ccccc1C2(C)C)C(C)(C)c1ccccc1C3(C)C]

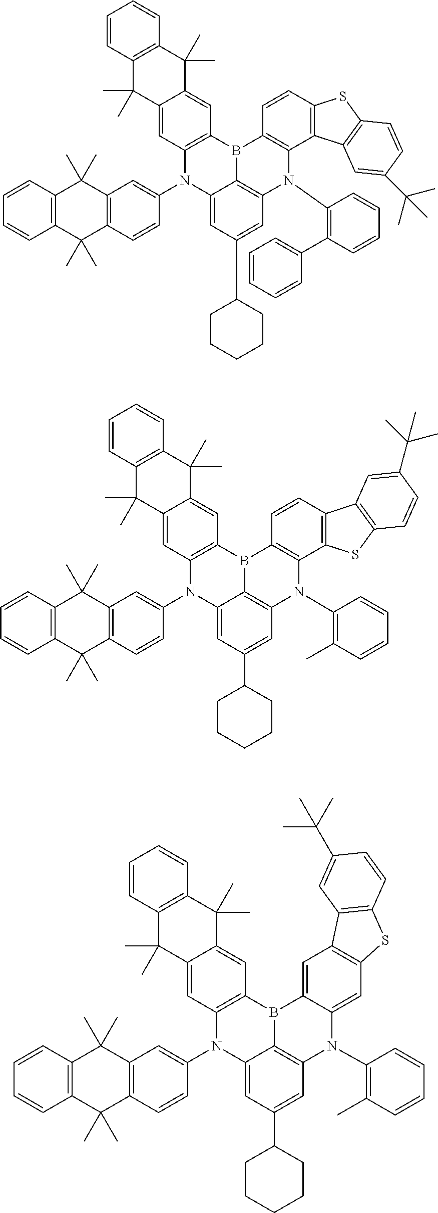 [SMILES: CC(C)(C)c1ccc2sc3ccc4c(c3c2c1)N(c1ccccc1-c1ccccc1)c1cc(C2CCCCC2)cc2c1B4c1cc3c(cc1N2c1ccc2c(c1)C(C)(C)c1ccccc1C2(C)C)C(C)(C)c1ccccc1C3(C)C ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3c(sc4ccc(C(C)(C)C)cc43)c21 ; Cc1ccccc1N1c2cc3sc4ccc(C(C)(C)C)cc4c3cc2B2c3cc4c(cc3N(c3ccc5c(c3)C(C)(C)c3ccccc3C5(C)C)c3cc(C5CCCCC5)cc1c32)C(C)(C)c1ccccc1C4(C)C]

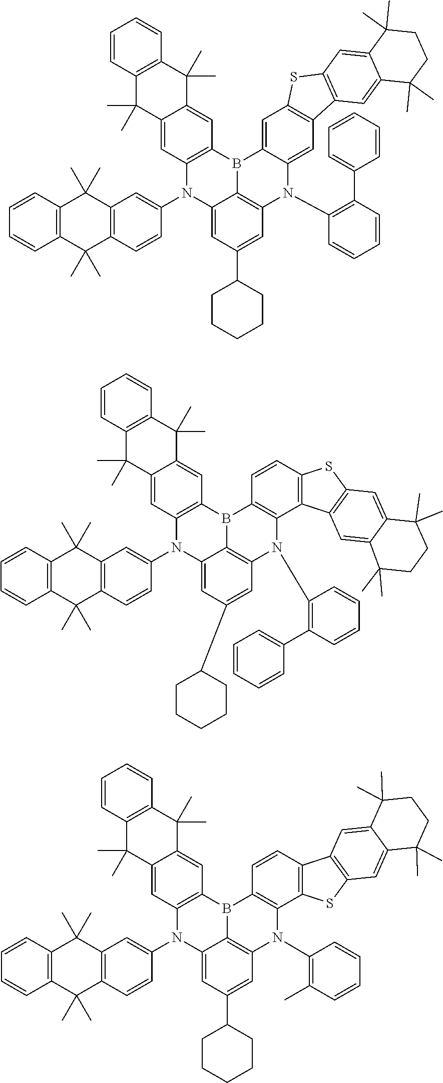 [SMILES: CC1(C)CCC(C)(C)c2cc3c(cc21)sc1cc2c(cc13)N(c1ccccc1-c1ccccc1)c1cc(C3CCCCC3)cc3c1B2c1cc2c(cc1N3c1ccc3c(c1)C(C)(C)c1ccccc1C3(C)C)C(C)(C)c1ccccc1C2(C)C ; CC1(C)CCC(C)(C)c2cc3c(cc21)sc1ccc2c(c13)N(c1ccccc1-c1ccccc1)c1cc(C3CCCCC3)cc3c1B2c1cc2c(cc1N3c1ccc3c(c1)C(C)(C)c1ccccc1C3(C)C)C(C)(C)c1ccccc1C2(C)C ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3c(sc4cc5c(cc43)C(C)(C)CCC5(C)C)c21]

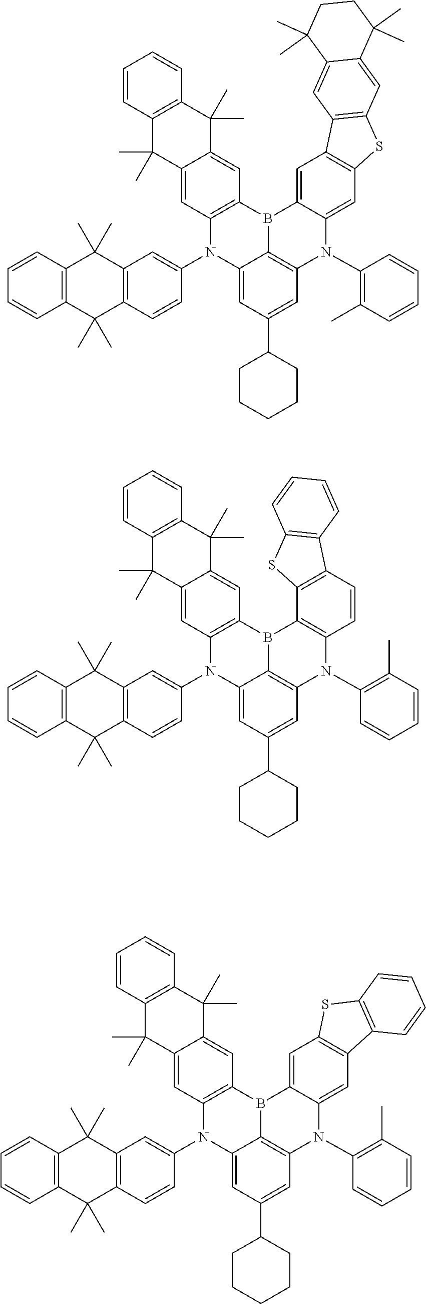 [SMILES: Cc1ccccc1N1c2cc3sc4cc5c(cc4c3cc2B2c3cc4c(cc3N(c3ccc6c(c3)C(C)(C)c3ccccc3C6(C)C)c3cc(C6CCCCC6)cc1c32)C(C)(C)c1ccccc1C4(C)C)C(C)(C)CCC5(C)C ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2c1ccc1c2sc2ccccc21 ; Cc1ccccc1N1c2cc3c(cc2B2c4cc5c(cc4N(c4ccc6c(c4)C(C)(C)c4ccccc4C6(C)C)c4cc(C6CCCCC6)cc1c42)C(C)(C)c1ccccc1C5(C)C)sc1ccccc13]

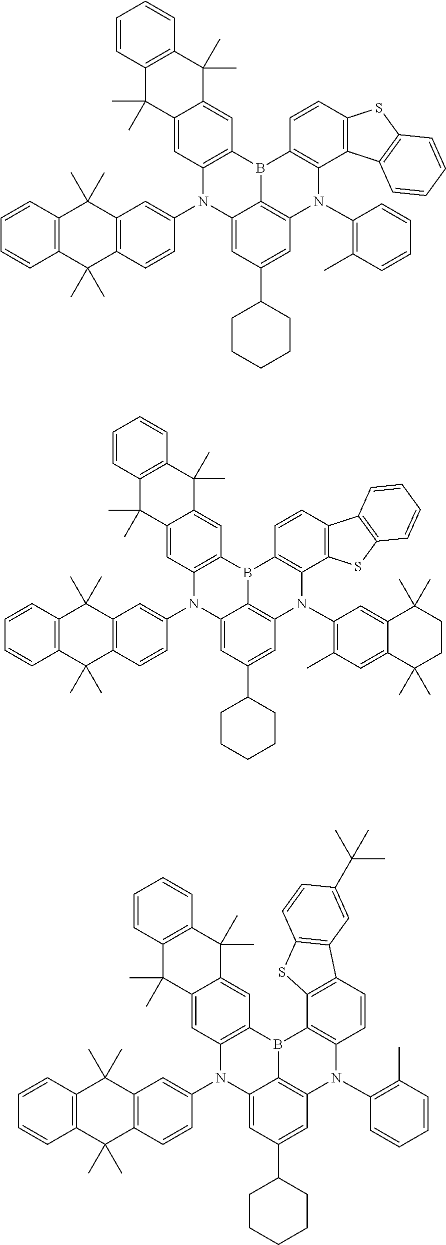 [SMILES: Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3sc4ccccc4c3c21 ; Cc1cc2c(cc1N1c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(sc5ccccc54)c31)C(C)(C)CCC2(C)C ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2c1ccc1c2sc2ccc(C(C)(C)C)cc21]

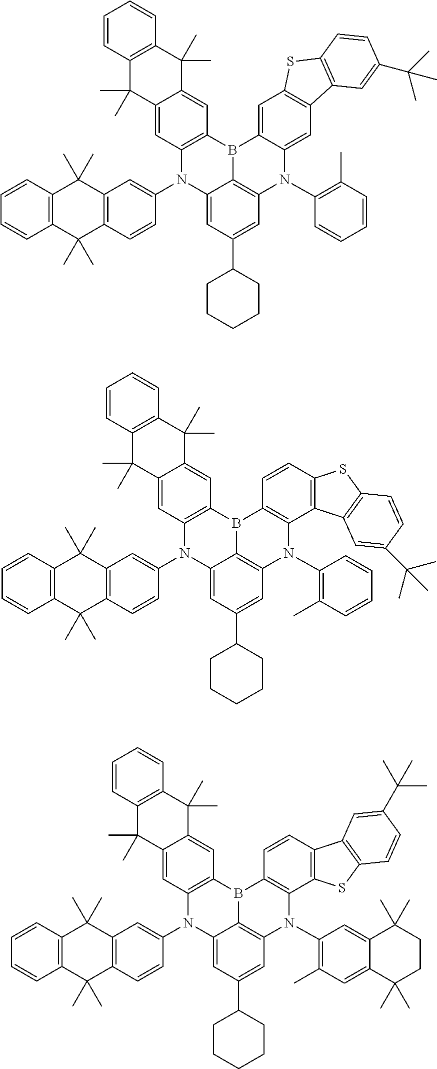 [SMILES: Cc1ccccc1N1c2cc3c(cc2B2c4cc5c(cc4N(c4ccc6c(c4)C(C)(C)c4ccccc4C6(C)C)c4cc(C6CCCCC6)cc1c42)C(C)(C)c1ccccc1C5(C)C)sc1ccc(C(C)(C)C)cc13 ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3sc4ccc(C(C)(C)C)cc4c3c21 ; Cc1cc2c(cc1N1c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(sc5ccc(C(C)(C)C)cc54)c31)C(C)(C)CCC2(C)C]

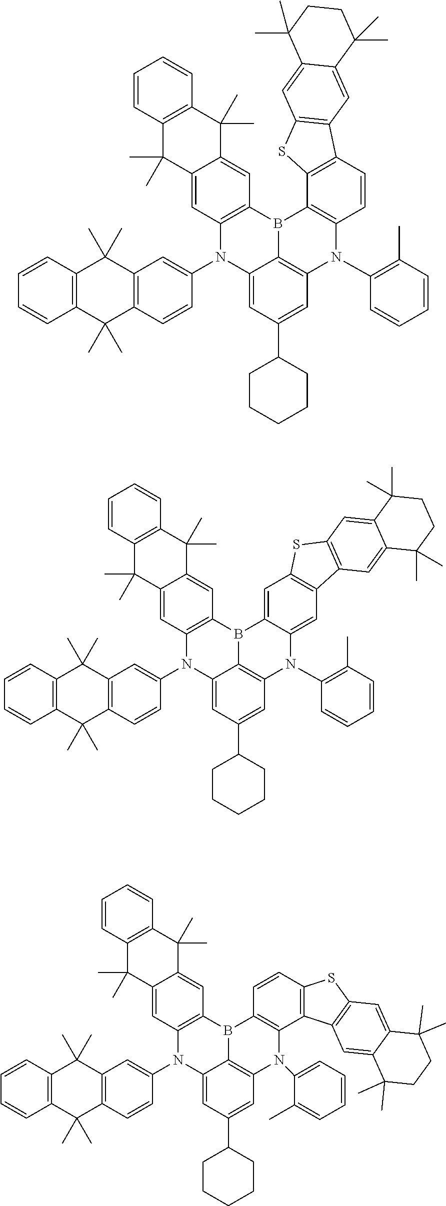 [SMILES: Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2c1ccc1c2sc2cc3c(cc21)C(C)(C)CCC3(C)C ; Cc1ccccc1N1c2cc3c(cc2B2c4cc5c(cc4N(c4ccc6c(c4)C(C)(C)c4ccccc4C6(C)C)c4cc(C6CCCCC6)cc1c42)C(C)(C)c1ccccc1C5(C)C)sc1cc2c(cc13)C(C)(C)CCC2(C)C ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3sc4cc5c(cc4c3c21)C(C)(C)CCC5(C)C]

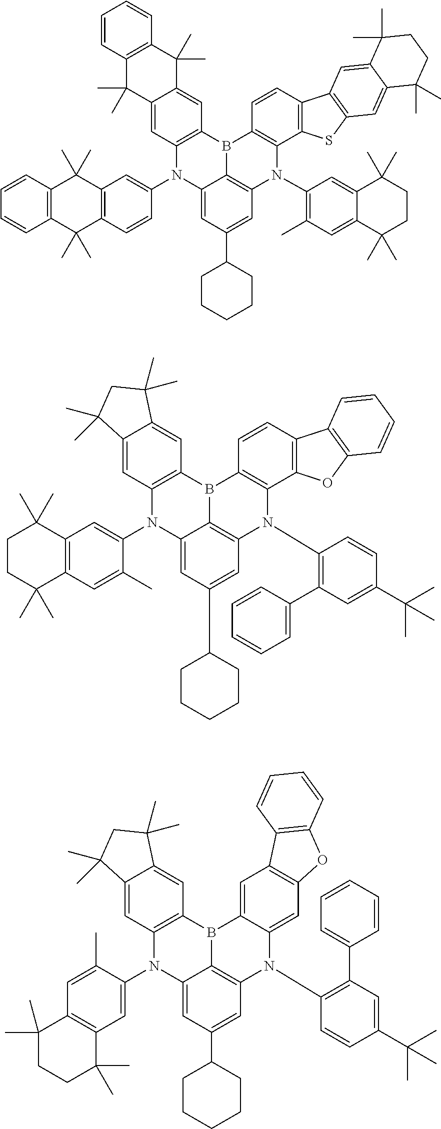

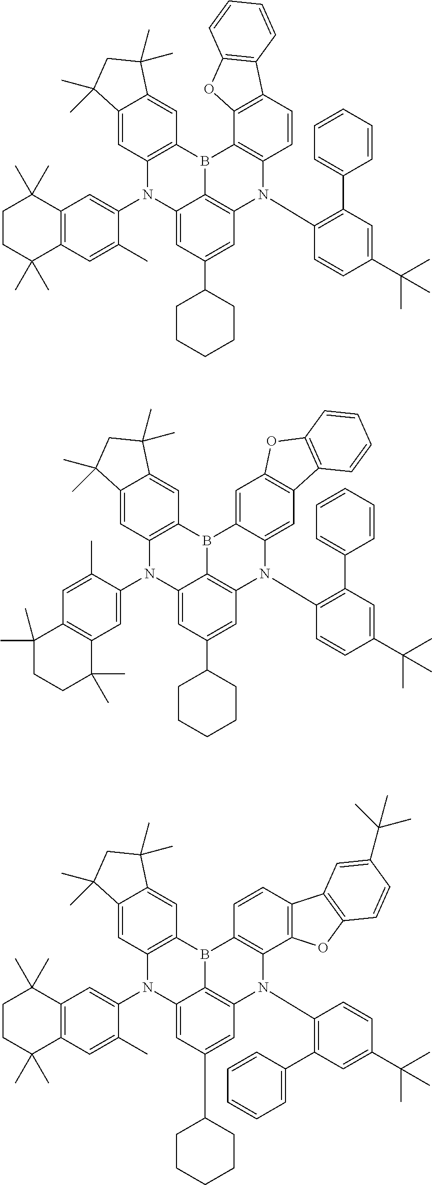

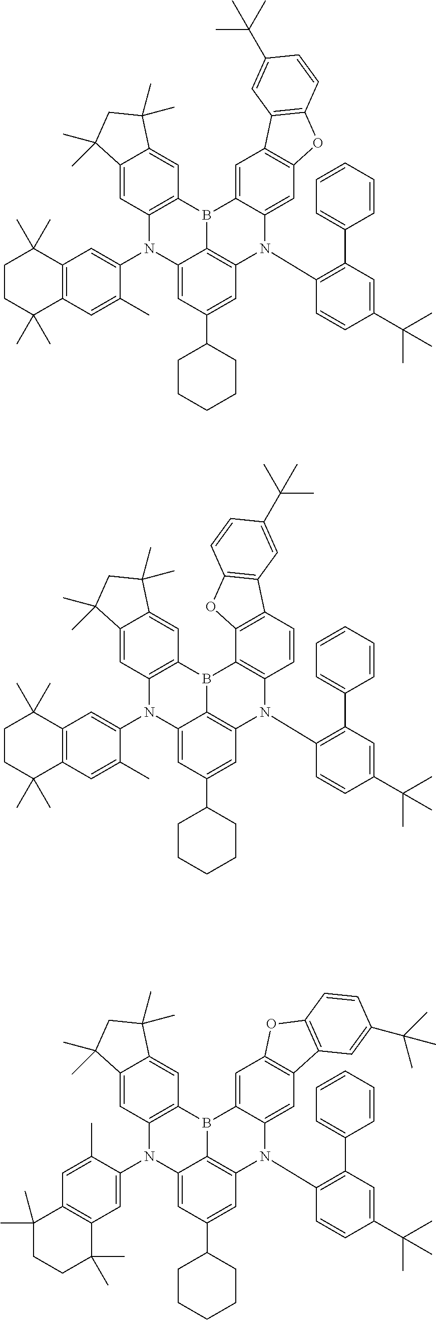

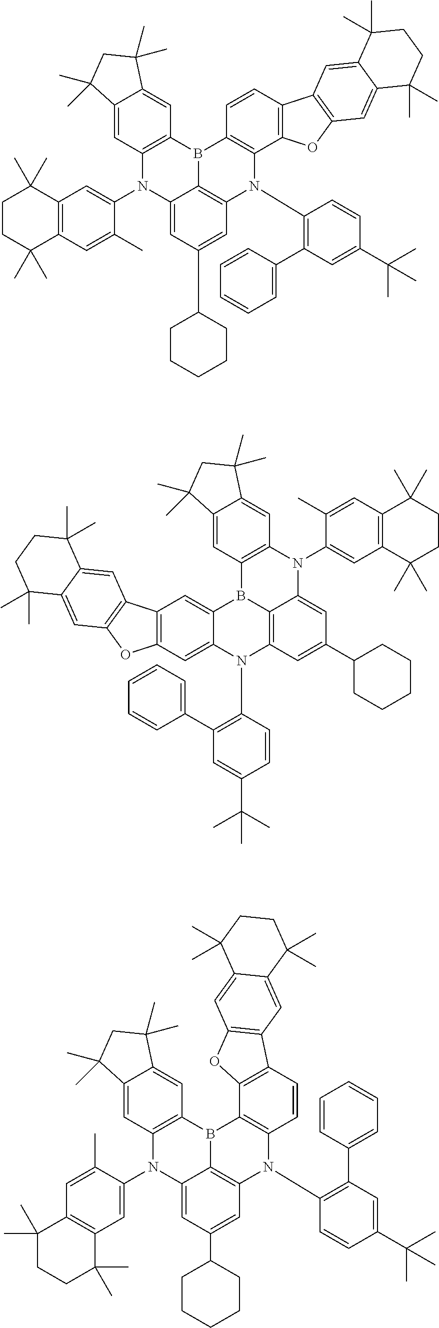

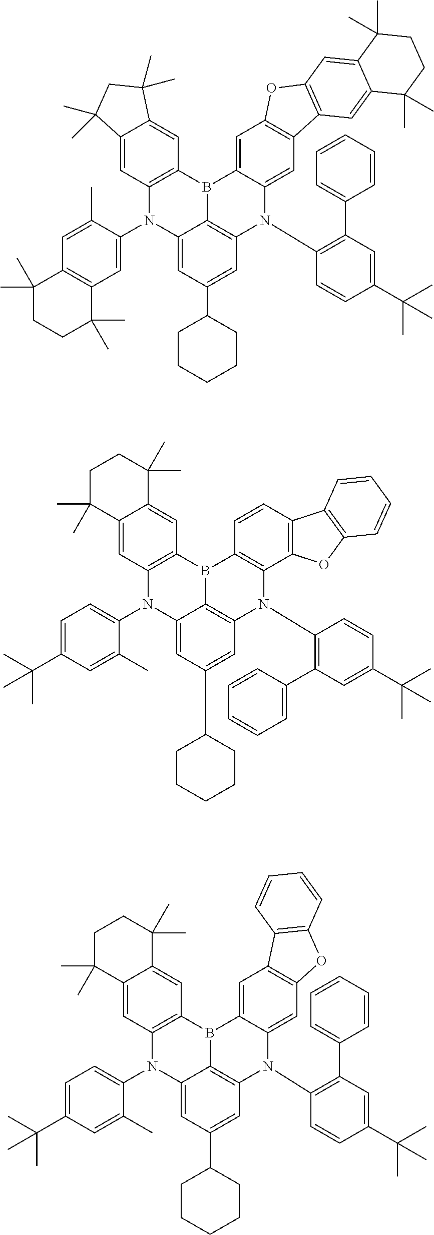

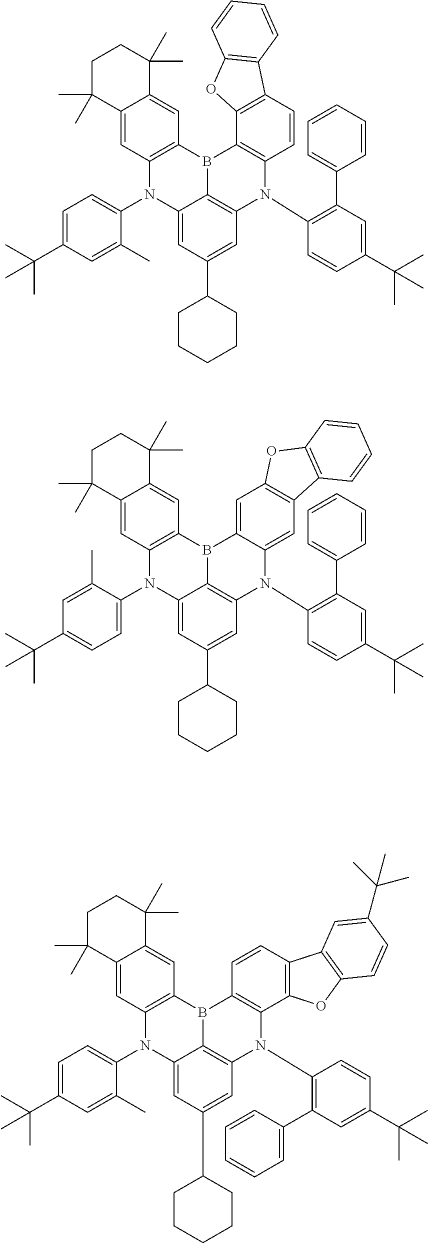

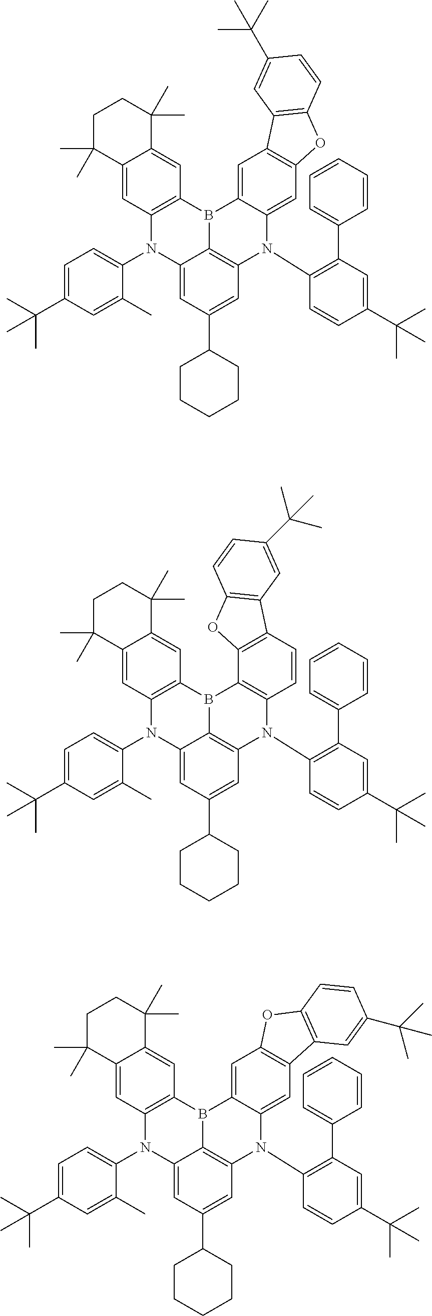

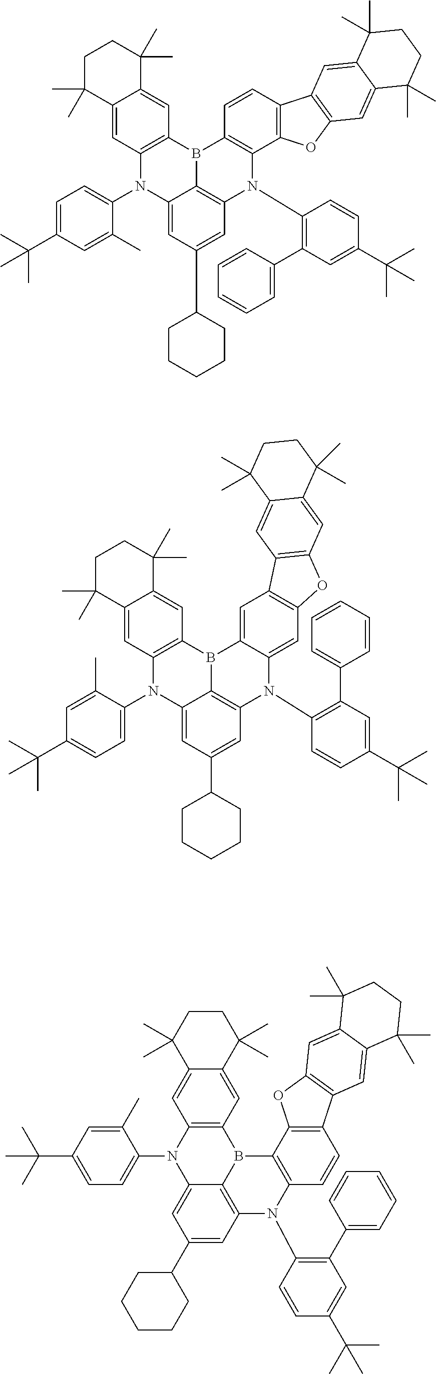

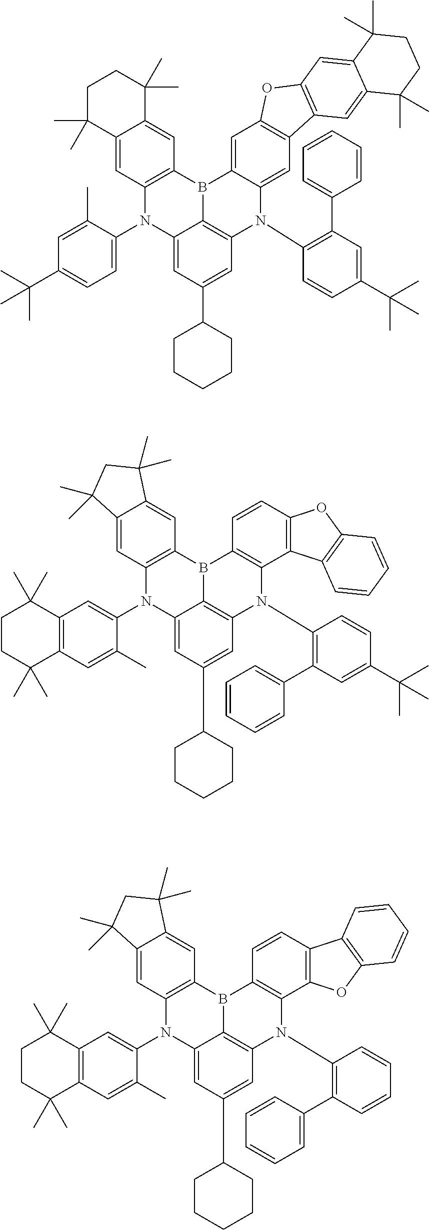 [SMILES: Cc1cc(C(C)(C)C)ccc1N1c2cc3c(cc2B2c4cc5oc6cc7c(cc6c5cc4N(c4ccc(C(C)(C)C)cc4-c4ccccc4)c4cc(C5CCCCC5)cc1c42)C(C)(C)CCC7(C)C)C(C)(C)CCC3(C)C ; Cc1cc2c(cc1N1c3cc4c(cc3B3c5ccc6oc7ccccc7c6c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5-c5ccccc5)c5cc(C6CCCCC6)cc1c53)C(C)(C)CC4(C)C)C(C)(C)CCC2(C)C]

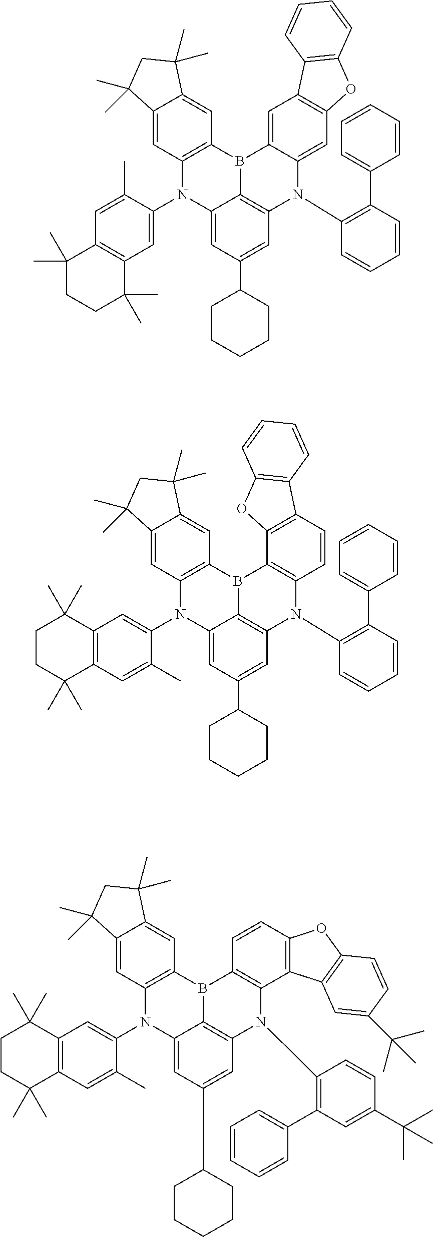 [SMILES: Cc1cc2c(cc1N1c3cc4c(cc3B3c5cc6c(cc5N(c5ccccc5-c5ccccc5)c5cc(C7CCCCC7)cc1c53)oc1ccccc16)C(C)(C)CC4(C)C)C(C)(C)CCC2(C)C ; Cc1cc2c(cc1N1c3cc4c(cc3B3c5c1cc(C1CCCCC1)cc5N(c1ccccc1-c1ccccc1)c1ccc5c(oc6ccccc65)c13)C(C)(C)CC4(C)C)C(C)(C)CCC2(C)C ; Cc1cc2c(cc1N1c3cc4c(cc3B3c5ccc6oc7ccc(C(C)(C)C)cc7c6c5N(c5ccc(C(C)(C)C)cc5-c5ccccc5)c5cc(C6CCCCC6)cc1c53)C(C)(C)CC4(C)C)C(C)(C)CCC2(C)C]

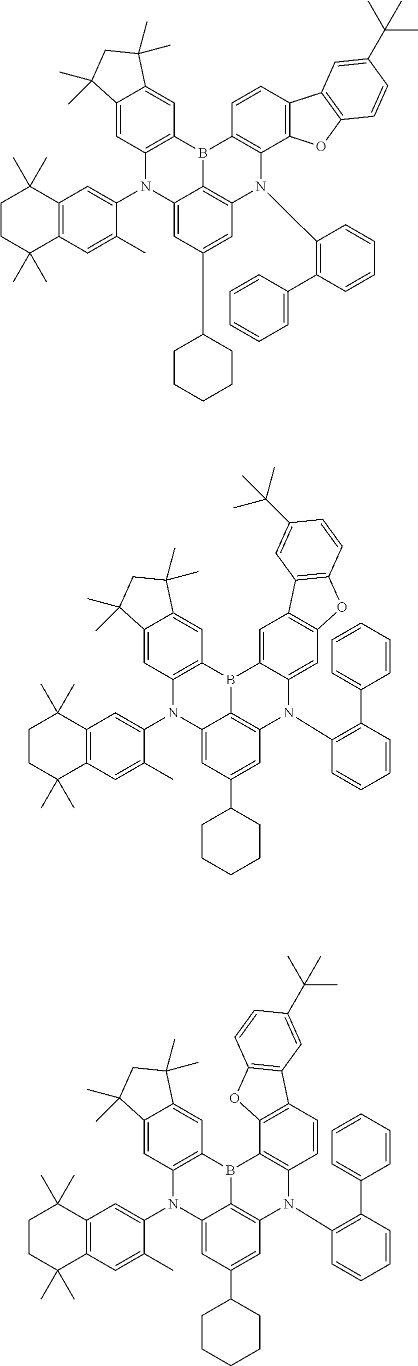 [SMILES: Cc1cc2c(cc1N1c3cc4c(cc3B3c5ccc6c(oc7ccc(C(C)(C)C)cc76)c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C7CCCCC7)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(C1CCCCC1)cc5N(c1ccccc1-c1ccccc1)c1ccc5c(oc6ccc(C(C)(C)C)cc65)c13)C(C)(C)CC4(C)C)C(C)(C)CCC2(C)C]

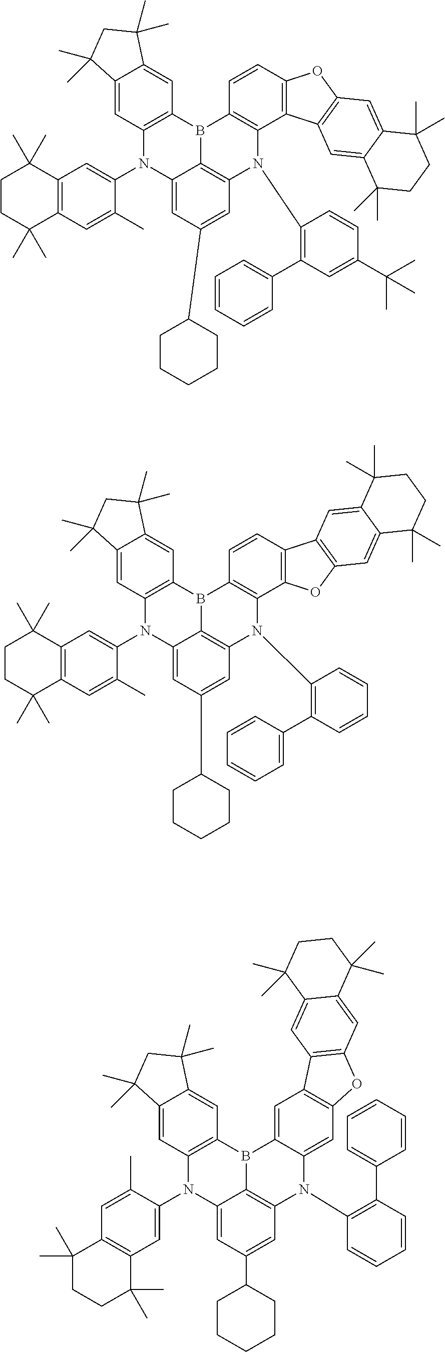

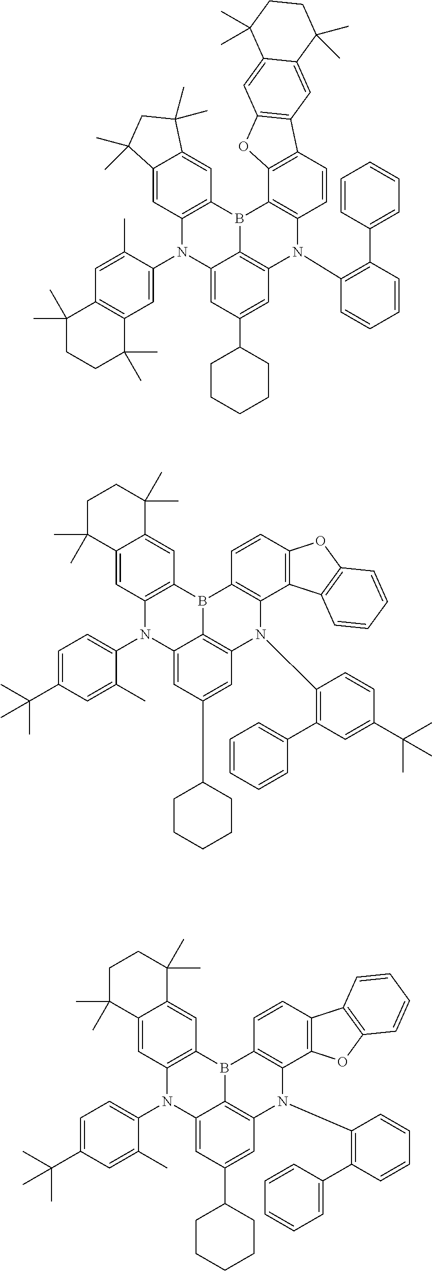

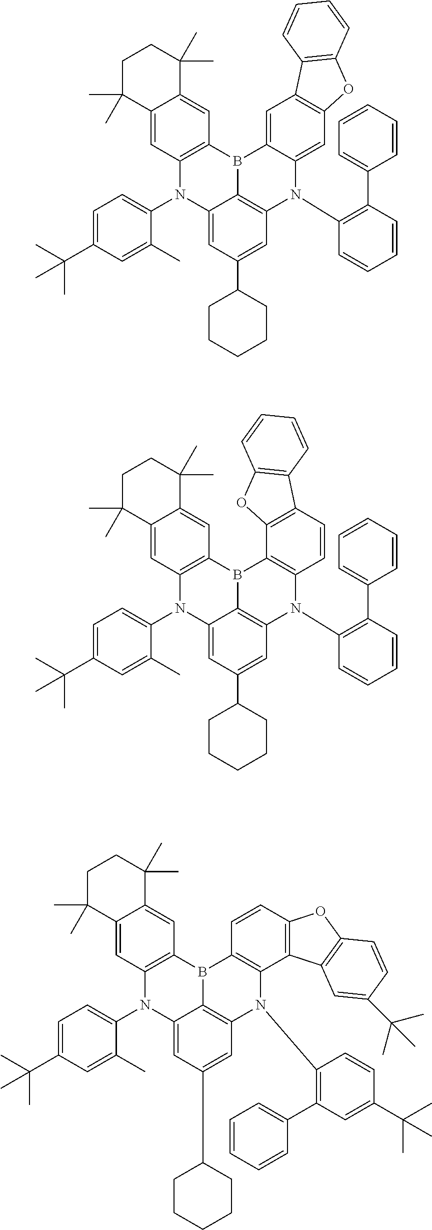 [SMILES: Cc1cc(C(C)(C)C)ccc1N1c2cc3c(cc2B2c4cc5c(cc4N(c4ccccc4-c4ccccc4)c4cc(C6CCCCC6)cc1c42)oc1ccccc15)C(C)(C)CCC3(C)C ; Cc1cc(C(C)(C)C)ccc1N1c2cc3c(cc2B2c4c1cc(C1CCCCC1)cc4N(c1ccccc1-c1ccccc1)c1ccc4c(oc5ccccc54)c12)C(C)(C)CCC3(C)C ; Cc1cc(C(C)(C)C)ccc1N1c2cc3c(cc2B2c4ccc5oc6ccc(C(C)(C)C)cc6c5c4N(c4ccc(C(C)(C)C)cc4-c4ccccc4)c4cc(C5CCCCC5)cc1c42)C(C)(C)CCC3(C)C]

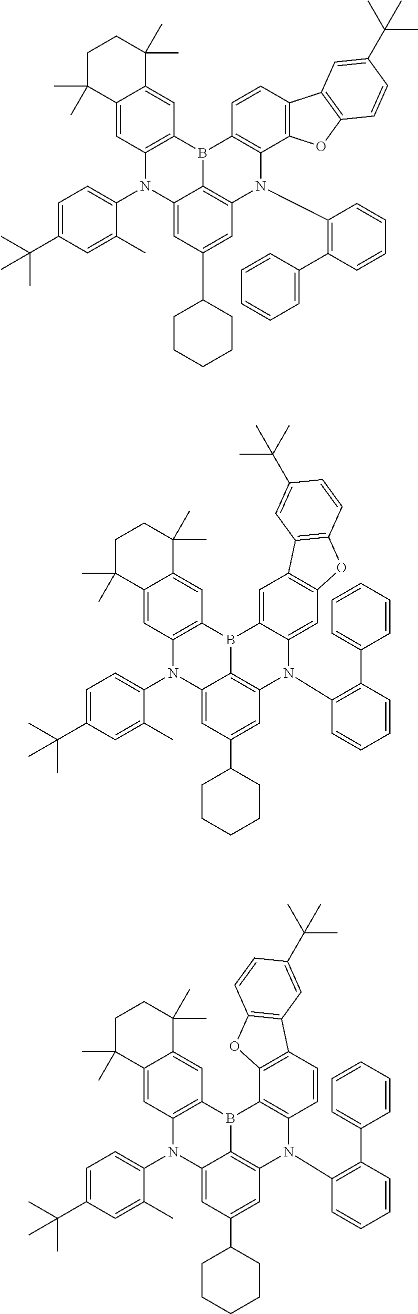

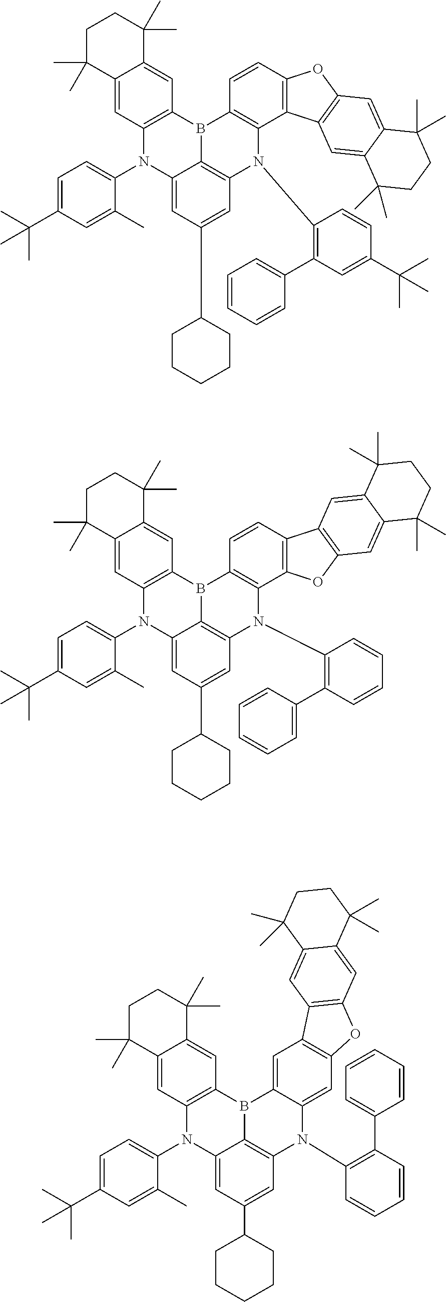

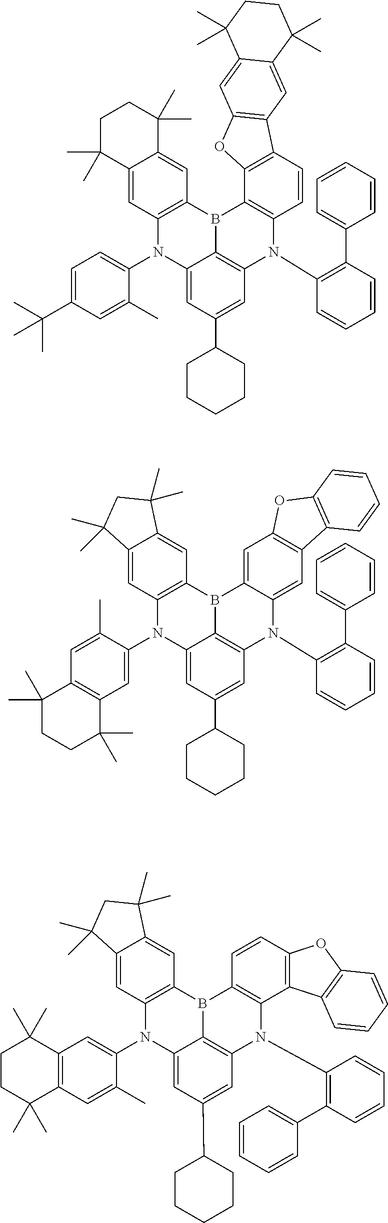 [SMILES: Cc1cc(C(C)(C)C)ccc1N1c2cc3c(cc2B2c4c1cc(C1CCCCC1)cc4N(c1ccccc1-c1ccccc1)c1ccc4c(oc5cc6c(cc54)C(C)(C)CCC6(C)C)c12)C(C)(C)CCC3(C)C ; Cc1cc2c(cc1N1c3cc4c(cc3B3c5cc6oc7ccccc7c6cc5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(C6CCCCC6)cc1c53)C(C)(C)CC4(C)C)C(C)(C)CCC2(C)C]

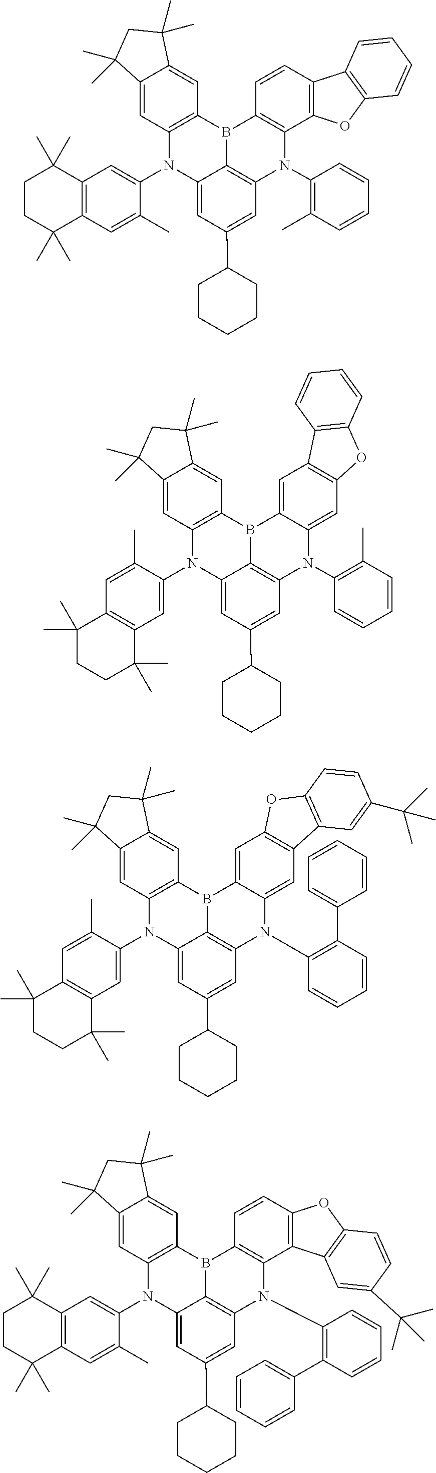 [SMILES: Cc1cc2c(cc1N1c3cc4c(cc3B3c5ccc6c(oc7ccccc76)c5N(c5ccccc5C)c5cc(C6CCCCC6)cc1c53)C(C)(C)CC4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(C5CCCCC5)cc1c32)C(C)(C)CC4(C)C ; Cc1cc2c(cc1N1c3cc4c(cc3B3c5cc6oc7ccc(C(C)(C)C)cc7c6cc5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6oc7ccc(C(C)(C)C)cc7c6c5N(c5ccccc5-c5ccccc5)c5cc(C6CCCCC6)cc1c53)C(C)(C)CC4(C)C)C(C)(C)CCC2(C)C]

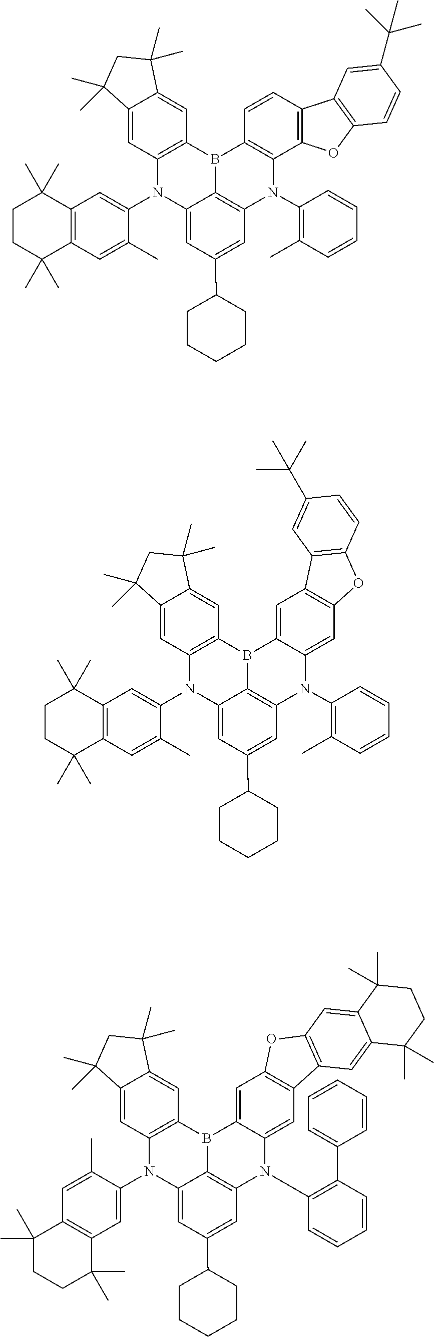

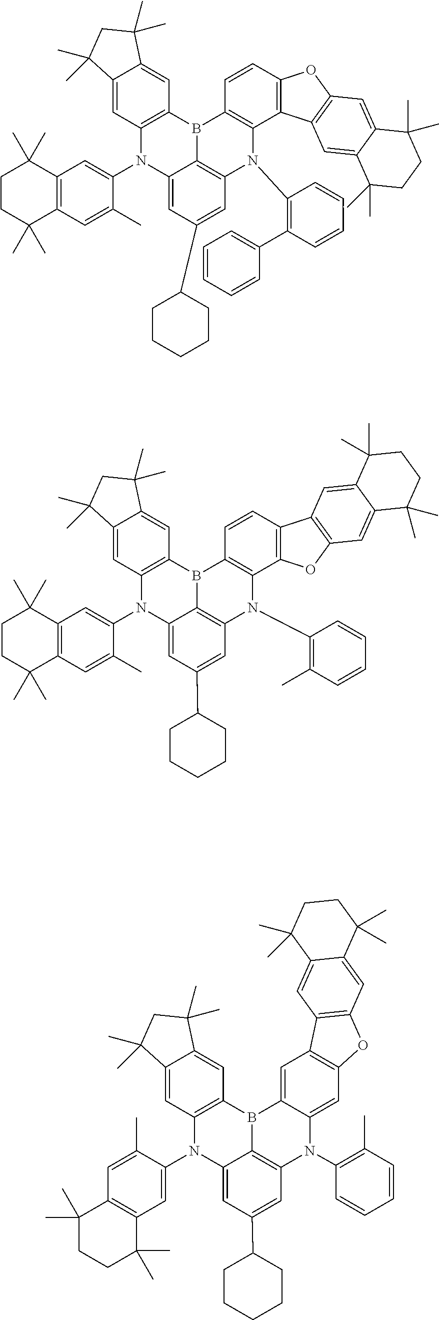

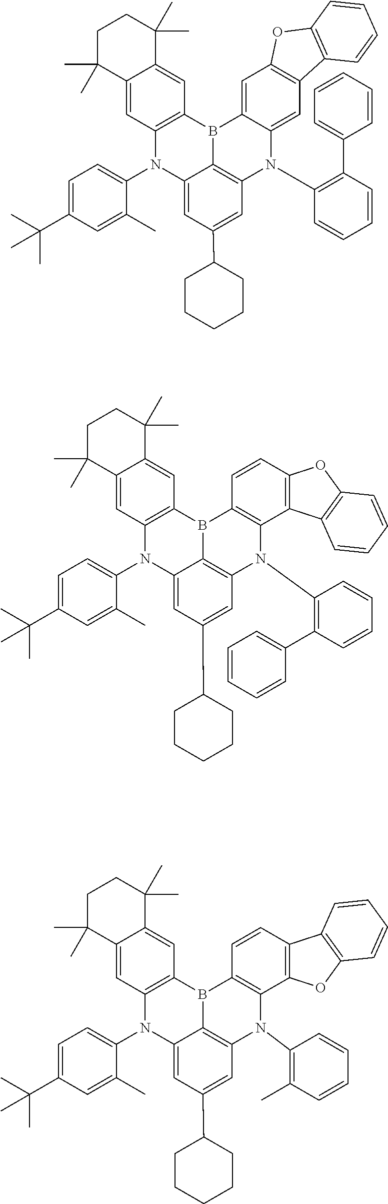 [SMILES: Cc1cc(C(C)(C)C)ccc1N1c2cc3c(cc2B2c4cc5oc6ccccc6c5cc4N(c4ccccc4-c4ccccc4)c4cc(C5CCCCC5)cc1c42)C(C)(C)CCC3(C)C ; Cc1cc(C(C)(C)C)ccc1N1c2cc3c(cc2B2c4ccc5oc6ccccc6c5c4N(c4ccccc4-c4ccccc4)c4cc(C5CCCCC5)cc1c42)C(C)(C)CCC3(C)C ; Cc1cc(C(C)(C)C)ccc1N1c2cc3c(cc2B2c4ccc5c(oc6ccccc65)c4N(c4ccccc4C)c4cc(C5CCCCC5)cc1c42)C(C)(C)CCC3(C)C]

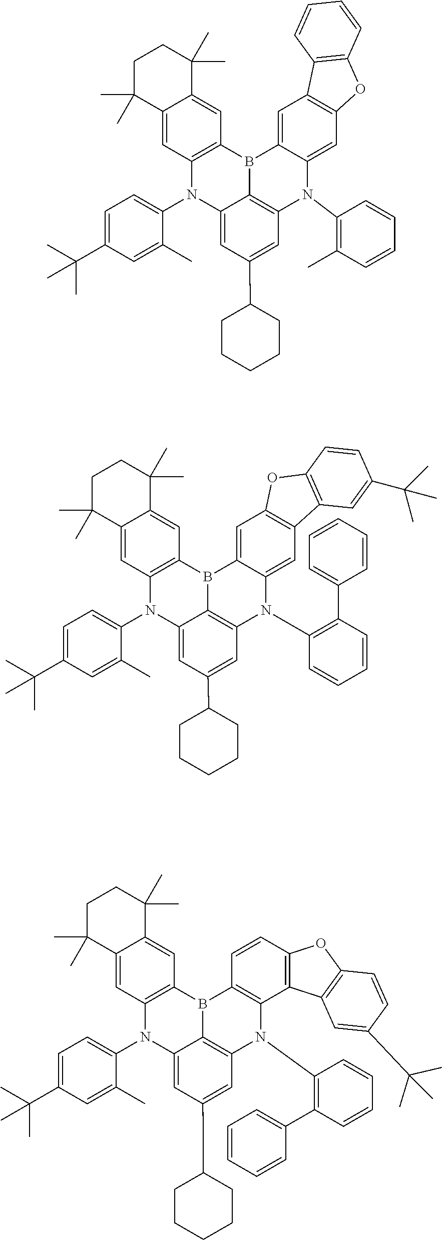

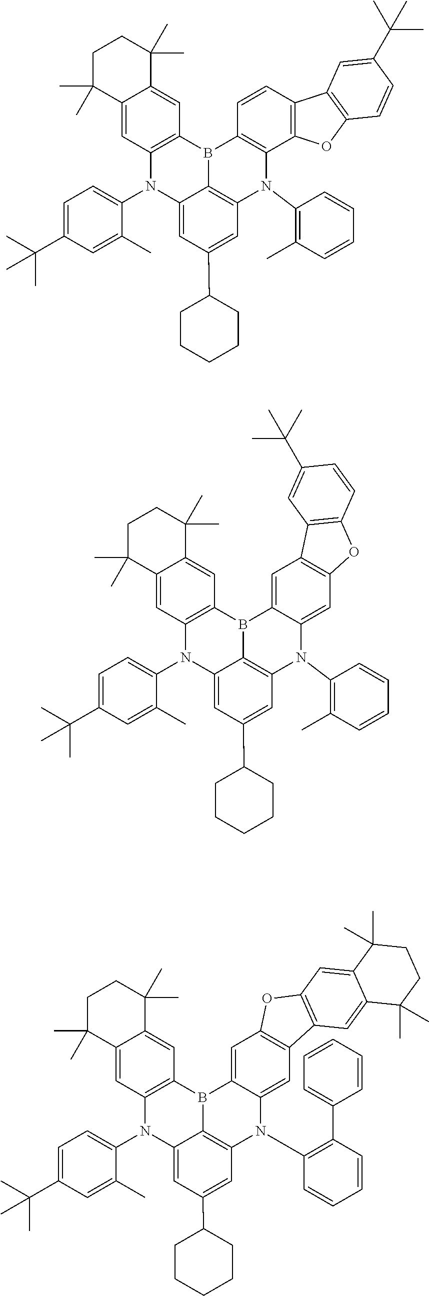

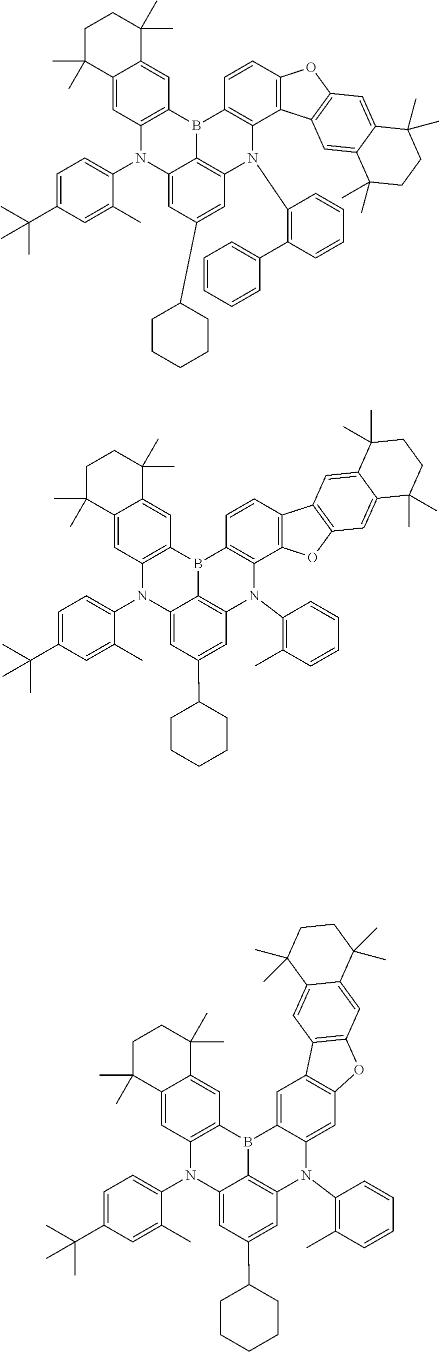

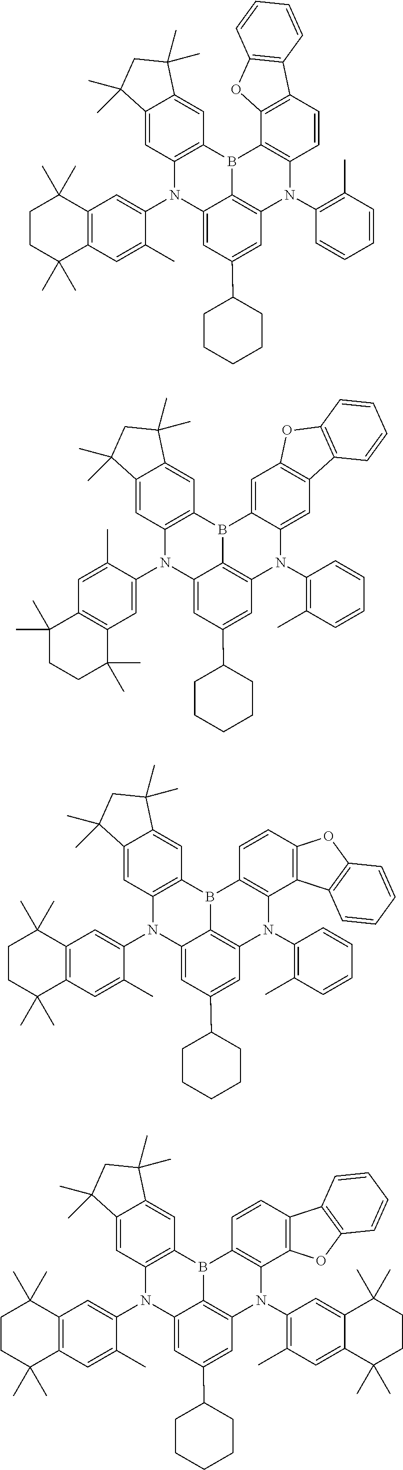 [SMILES: Cc1cc2c(cc1N1c3cc4c(cc3B3c5c1cc(C1CCCCC1)cc5N(c1ccccc1C)c1ccc5c(oc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)CC5(C)C)oc1ccccc13 ; Cc1cc2c(cc1N1c3cc4c(cc3B3c5ccc6oc7ccccc7c6c5N(c5ccccc5C)c5cc(C6CCCCC6)cc1c53)C(C)(C)CC4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(C6CCCCC6)cc1c53)C(C)(C)CC4(C)C)C(C)(C)CCC2(C)C]

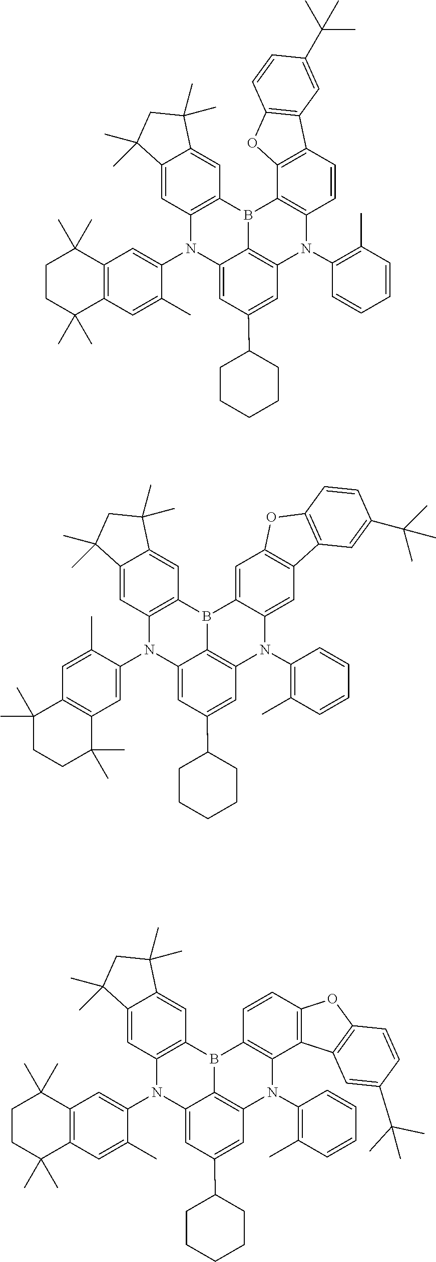 [SMILES: Cc1cc2c(cc1N1c3cc4c(cc3B3c5c1cc(C1CCCCC1)cc5N(c1ccccc1C)c1ccc5c(oc6ccc(C(C)(C)C)cc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)CC5(C)C)oc1ccc(C(C)(C)C)cc13 ; Cc1cc2c(cc1N1c3cc4c(cc3B3c5ccc6oc7ccc(C(C)(C)C)cc7c6c5N(c5ccccc5C)c5cc(C6CCCCC6)cc1c53)C(C)(C)CC4(C)C)C(C)(C)CCC2(C)C]

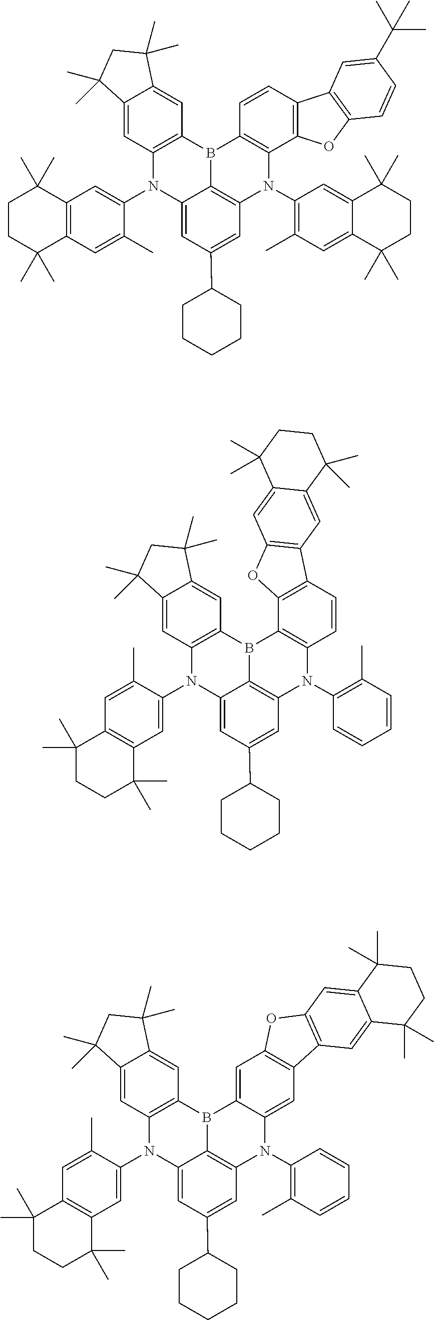

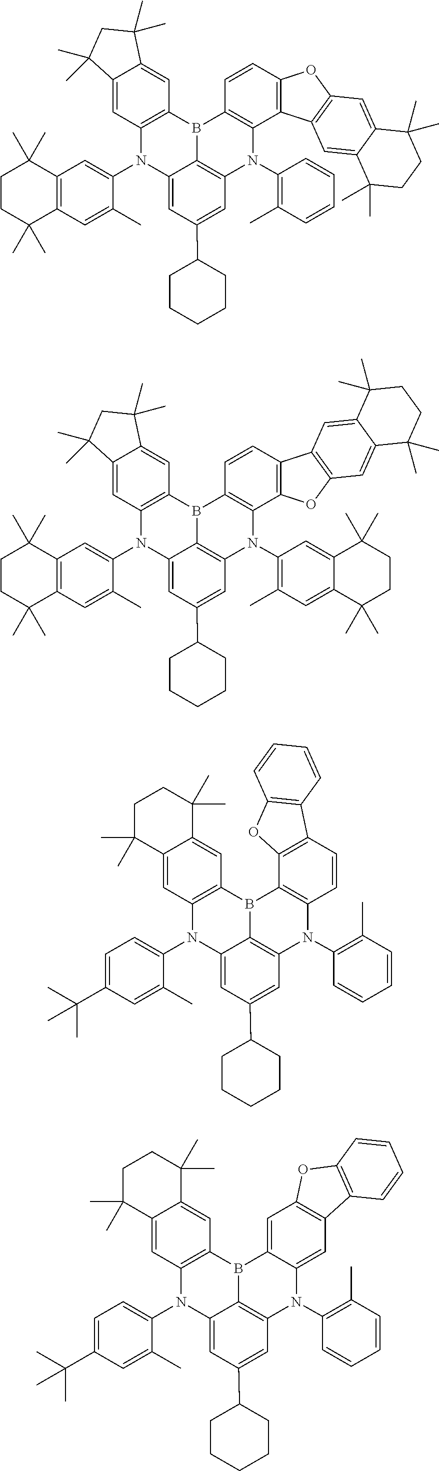

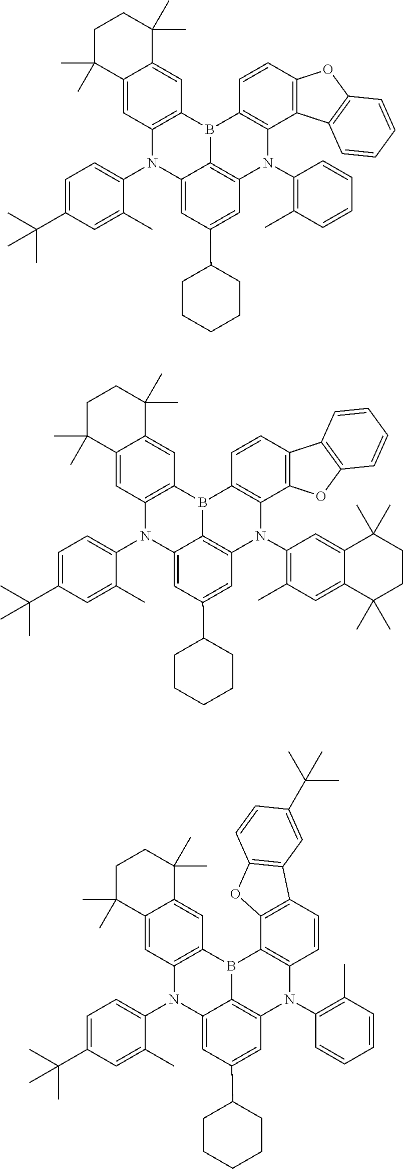 [SMILES: Cc1cc(C(C)(C)C)ccc1N1c2cc3c(cc2B2c4ccc5oc6ccccc6c5c4N(c4ccccc4C)c4cc(C5CCCCC5)cc1c42)C(C)(C)CCC3(C)C ; Cc1cc(C(C)(C)C)ccc1N1c2cc3c(cc2B2c4ccc5c(oc6ccccc65)c4N(c4cc5c(cc4C)C(C)(C)CCC5(C)C)c4cc(C5CCCCC5)cc1c42)C(C)(C)CCC3(C)C ; Cc1cc(C(C)(C)C)ccc1N1c2cc3c(cc2B2c4c1cc(C1CCCCC1)cc4N(c1ccccc1C)c1ccc4c(oc5ccc(C(C)(C)C)cc54)c12)C(C)(C)CCC3(C)C]

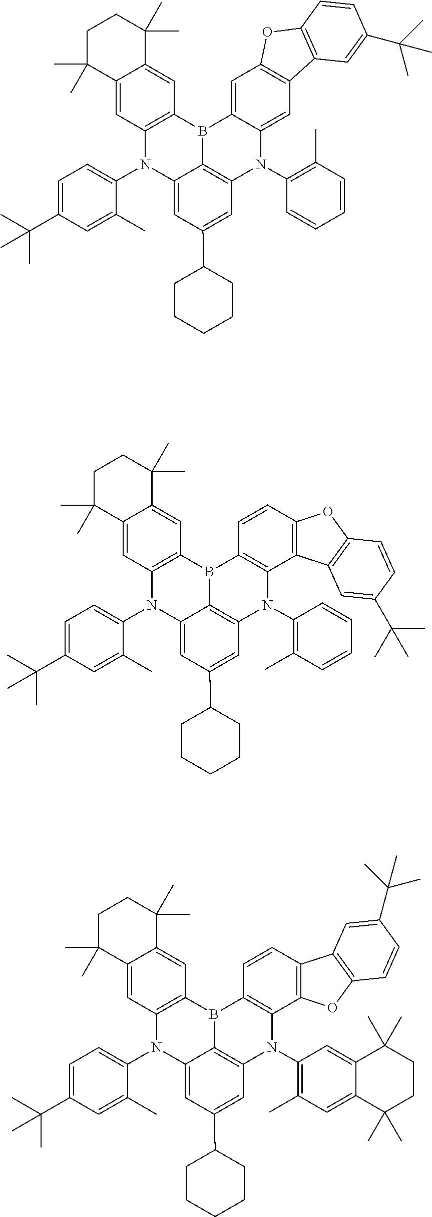

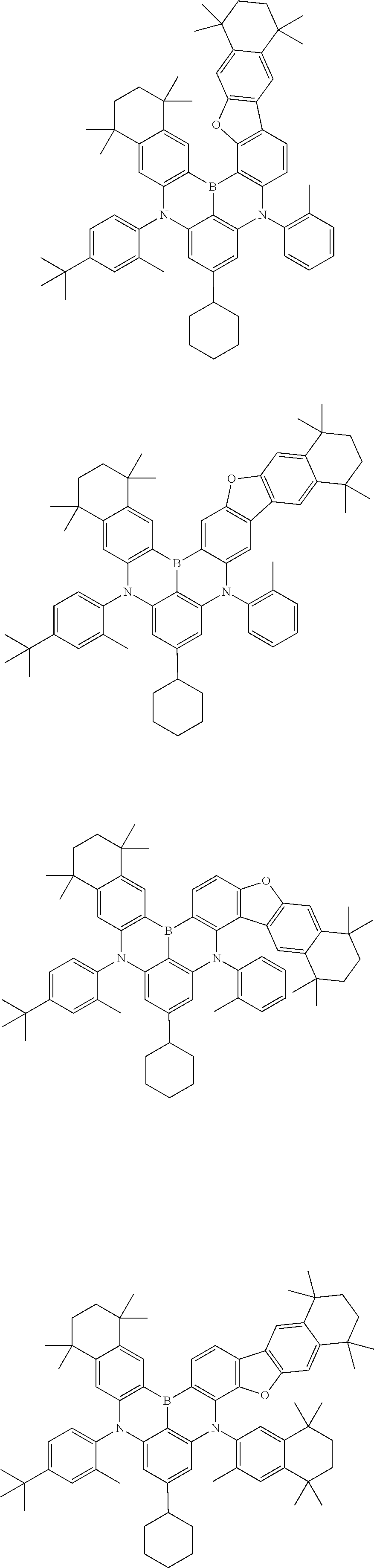

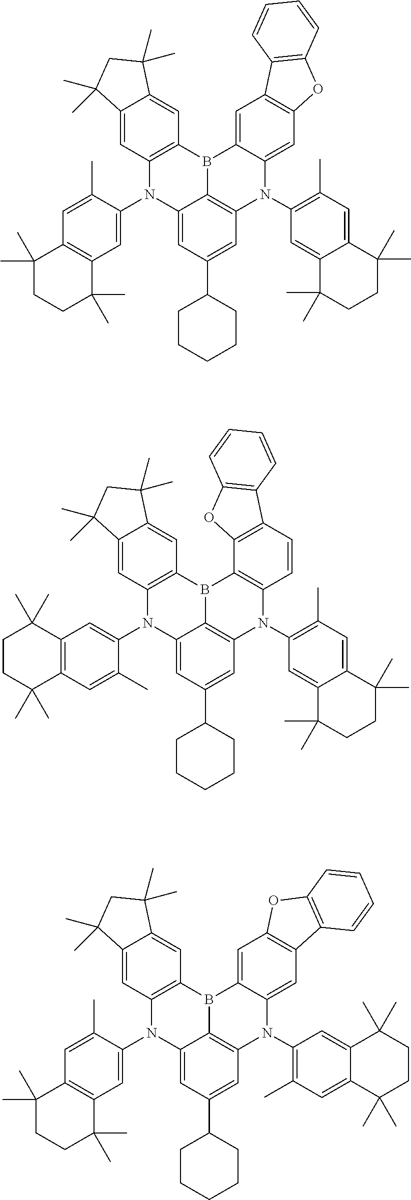

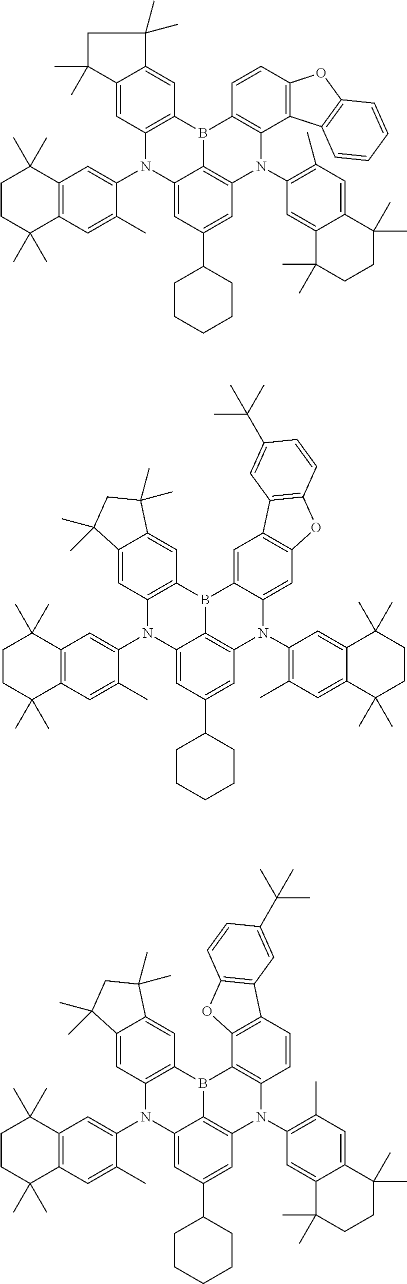 [SMILES: Cc1cc2c(cc1N1c3cc4c(cc3B3c5ccc6oc7ccccc7c6c5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C7CCCCC7)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(C1CCCCC1)cc5N(c1cc5c(cc1C)C(C)(C)CCC5(C)C)c1ccc5c(oc6ccc(C(C)(C)C)cc65)c13)C(C)(C)CC4(C)C)C(C)(C)CCC2(C)C]

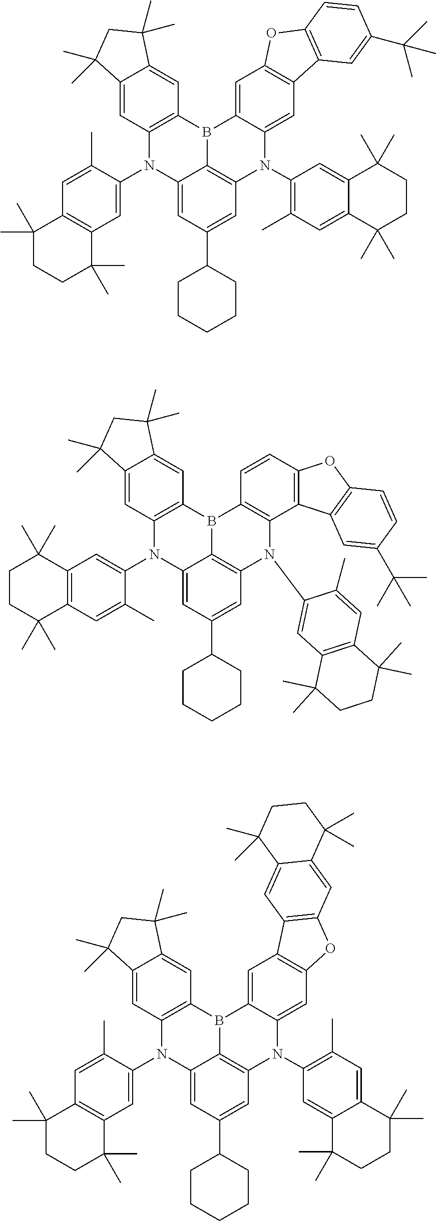

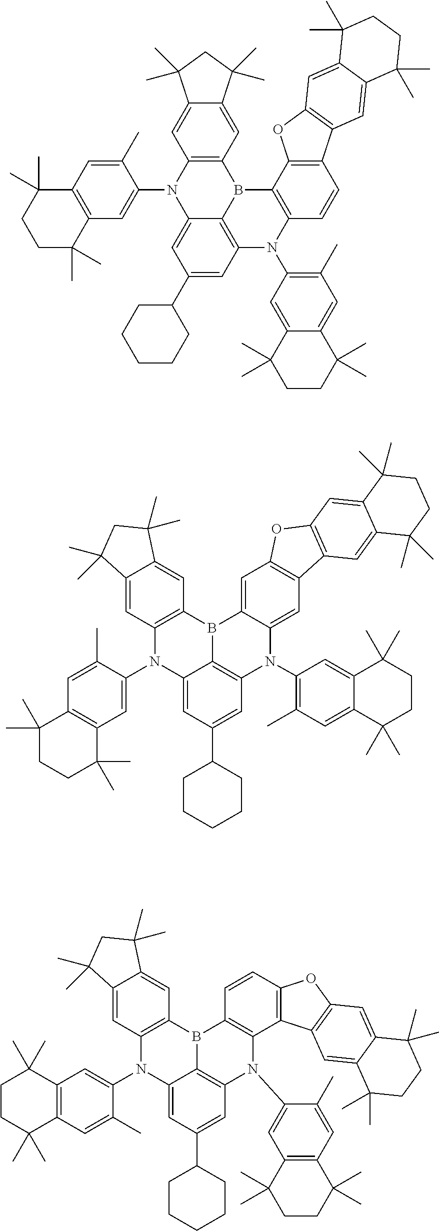

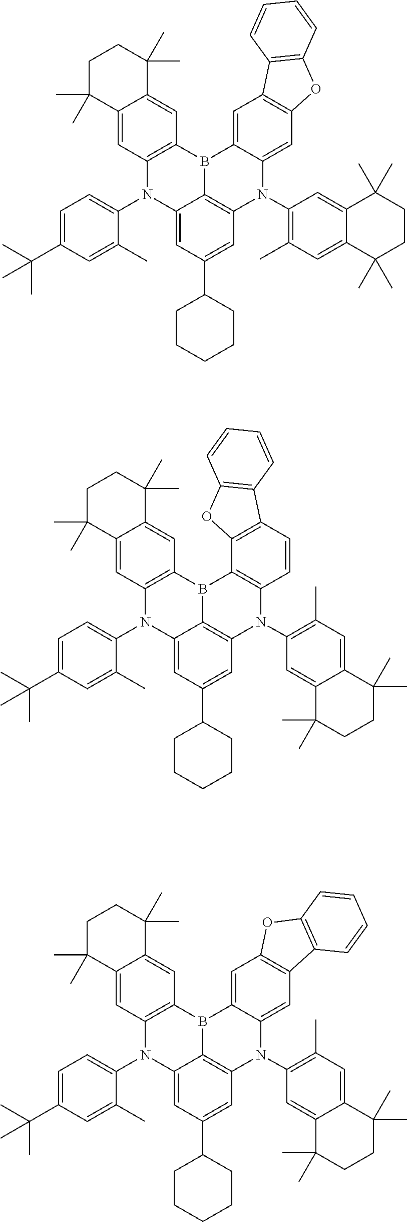

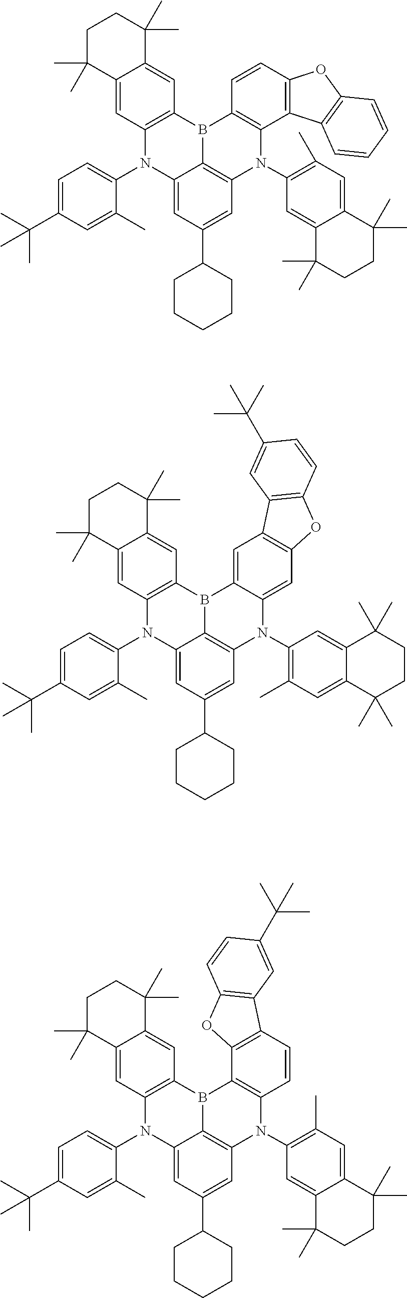

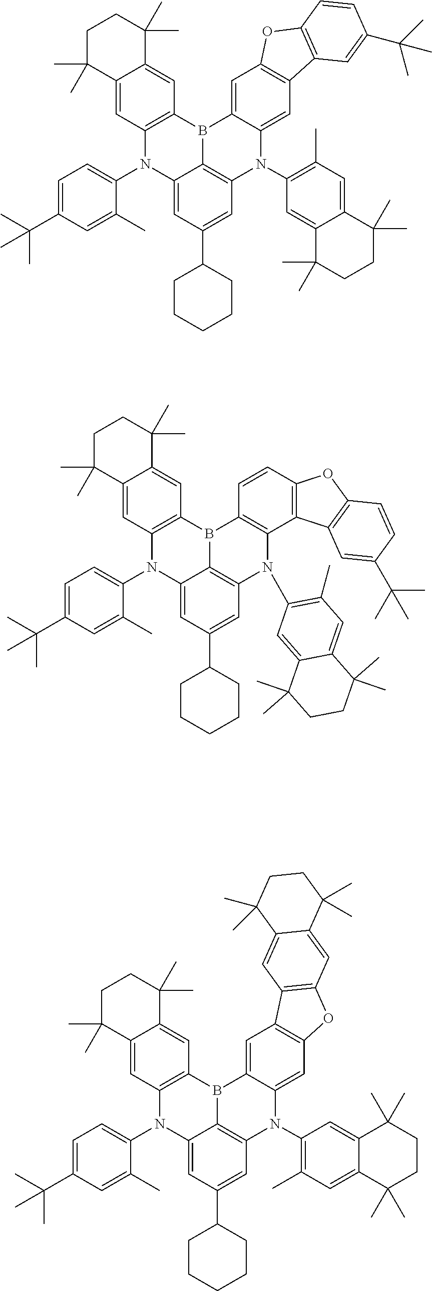

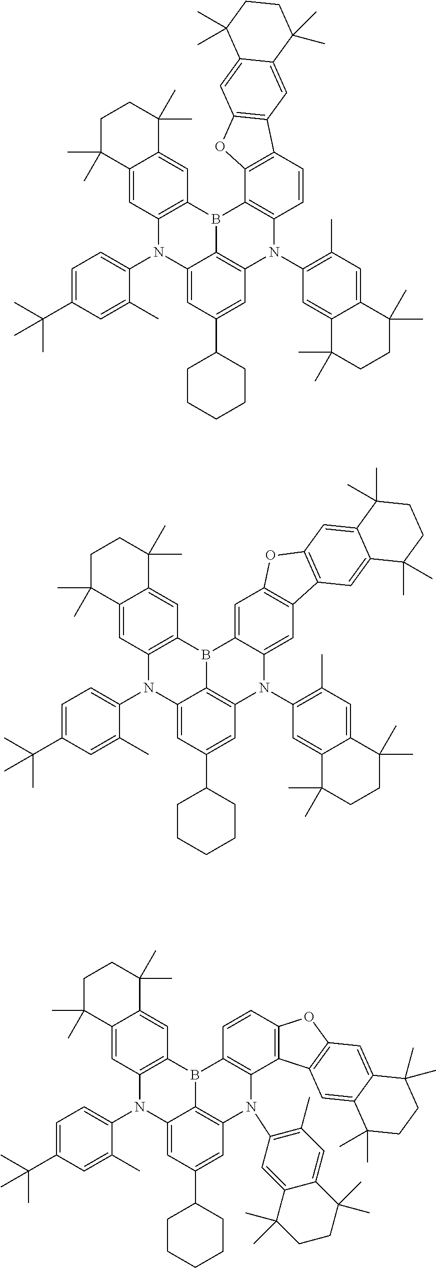

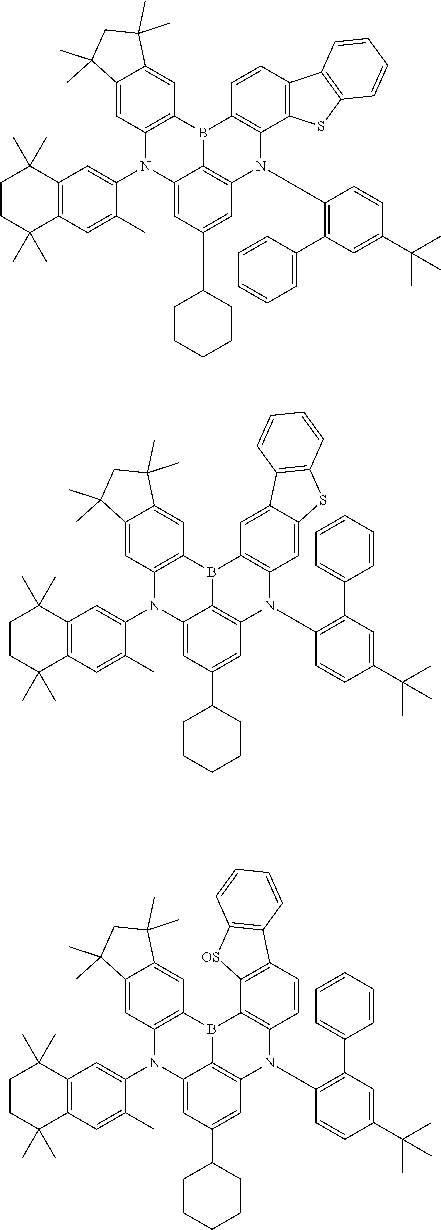

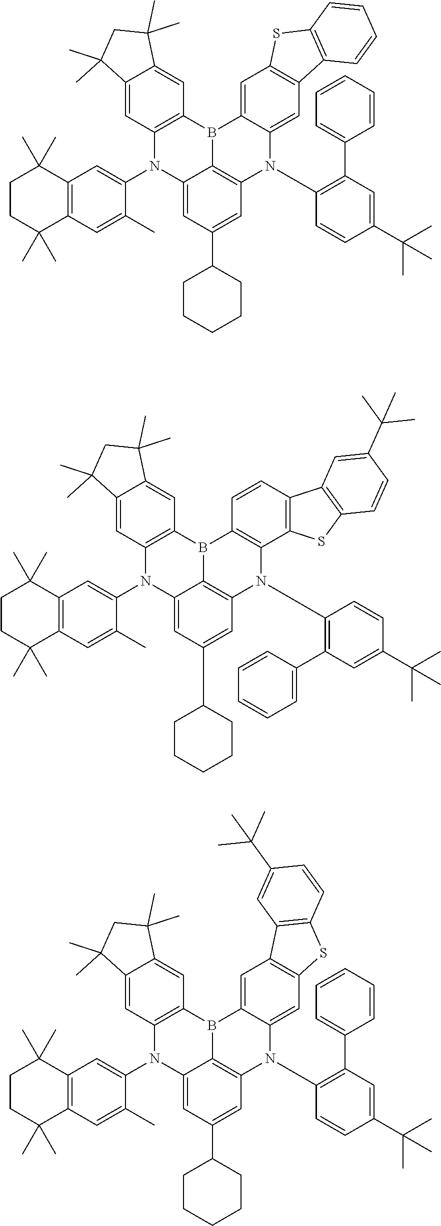 [SMILES: Cc1cc2c(cc1N1c3cc4c(cc3B3c5cc6sc7ccccc7c6cc5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)sc1ccc(C(C)(C)C)cc16)C(C)(C)CC4(C)C)C(C)(C)CCC2(C)C]

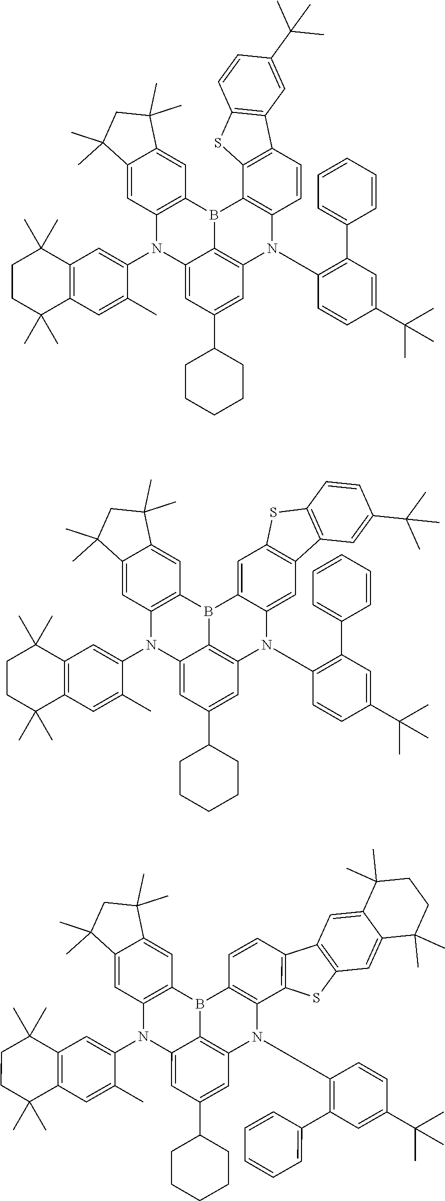 [SMILES: Cc1cc2c(cc1N1c3cc4c(cc3B3c5c1cc(C1CCCCC1)cc5N(c1ccc(C(C)(C)C)cc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(C6CCCCC6)cc1c53)C(C)(C)CC4(C)C)C(C)(C)CCC2(C)C]

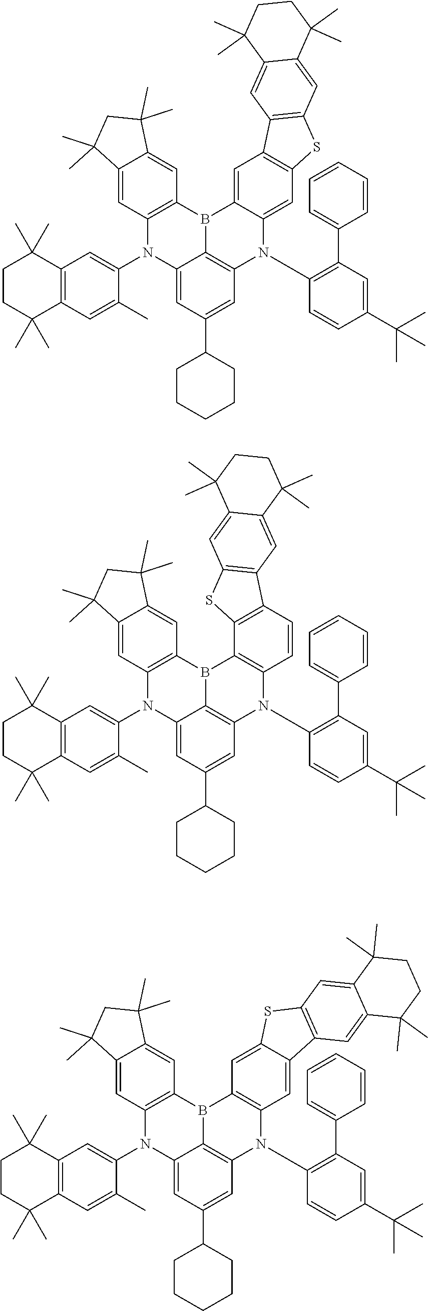

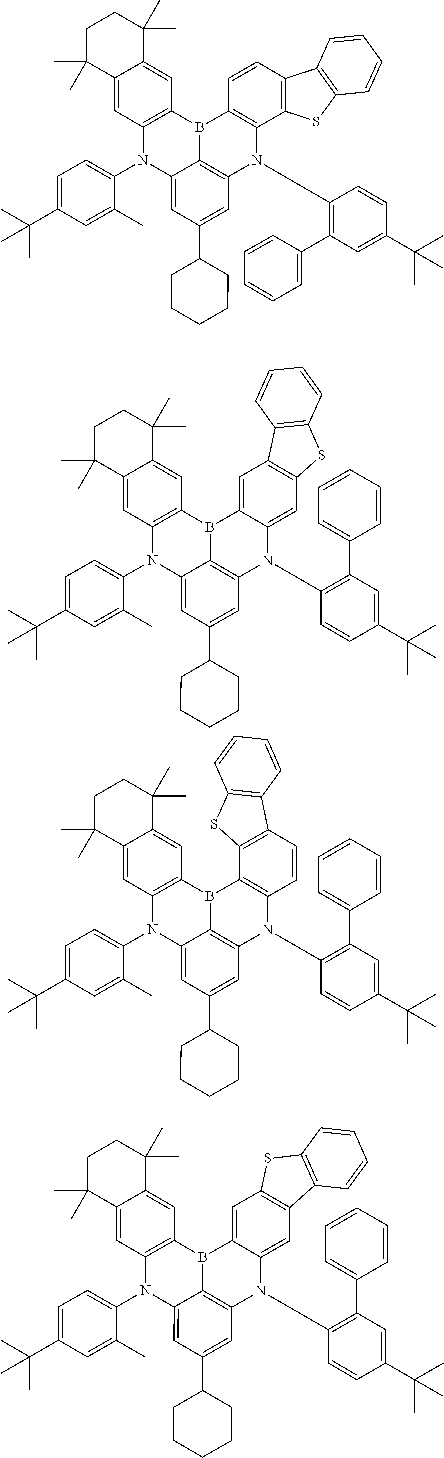

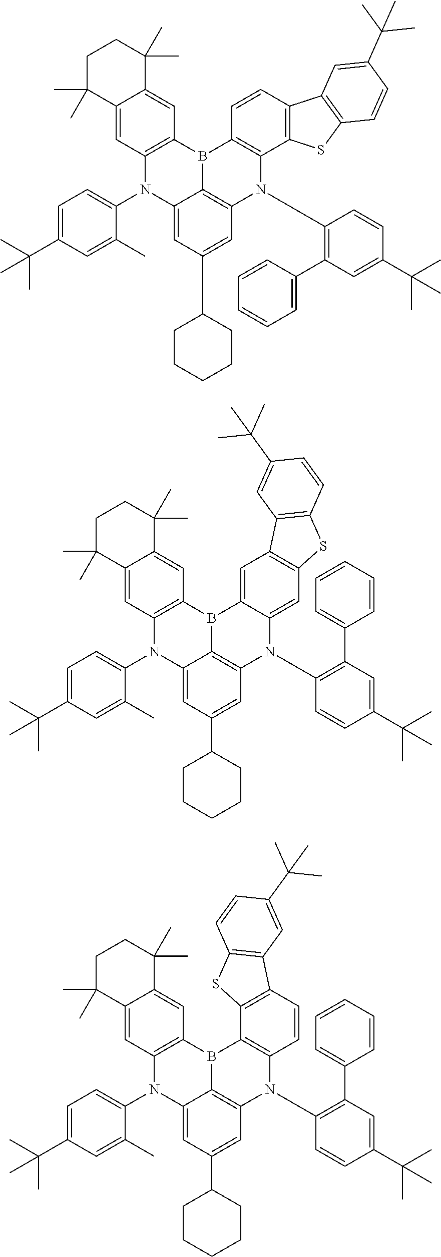

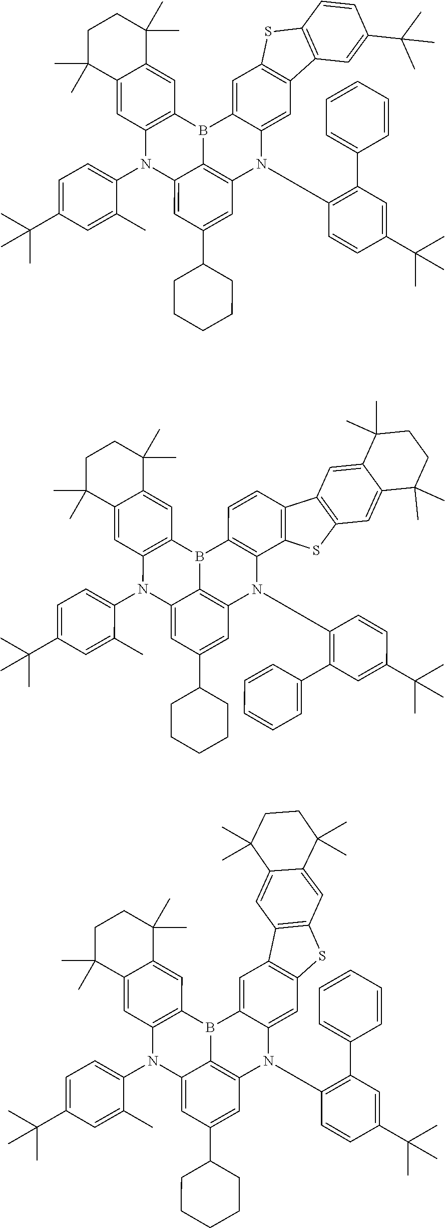

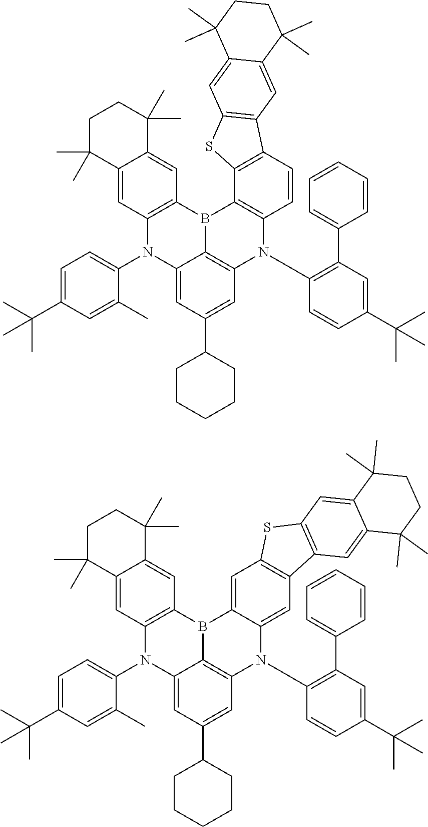

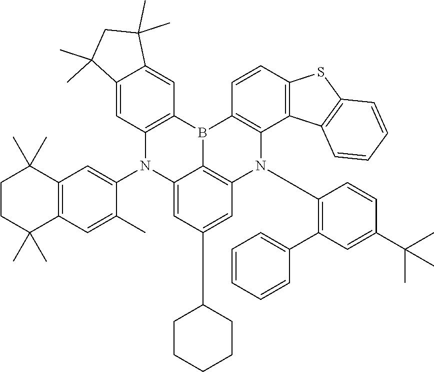 [SMILES: Cc1cc2c(cc1N1c3cc4c(cc3B3c5ccc6sc7ccccc7c6c5N(Cc5ccc(C(C)(C)C)cc5-c5ccccc5)c5cc(C6CCCCC6)cc1c53)C(C)(C)CC4(C)C)C(C)(C)CCC2(C)C]

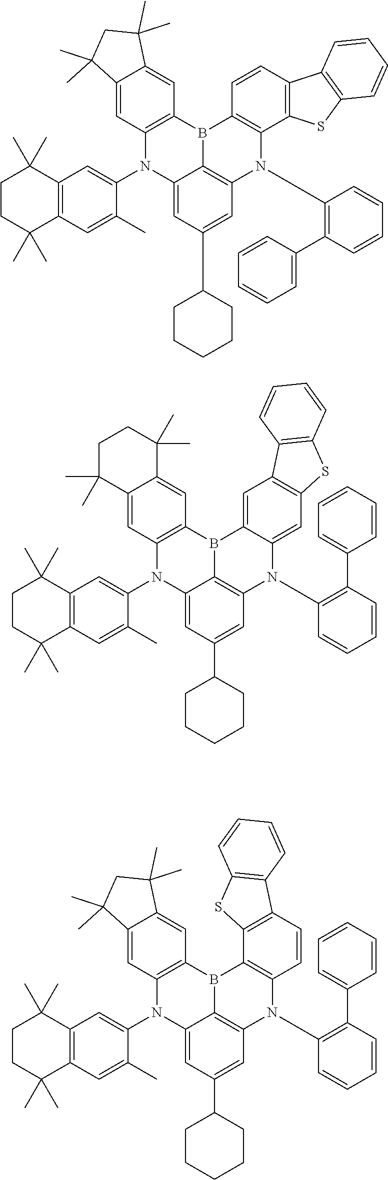

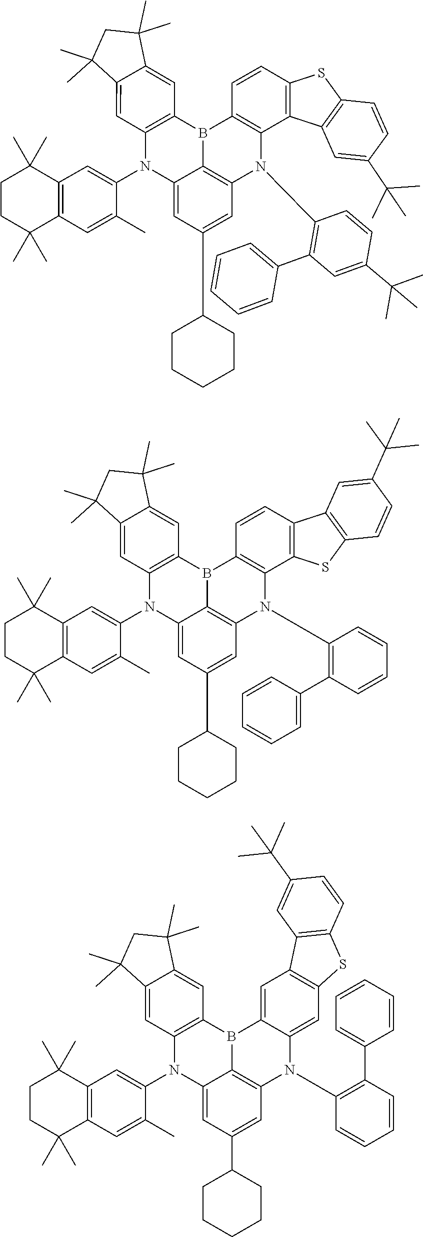 [SMILES: Cc1cc2c(cc1N1c3cc4c(cc3B3c5ccc6sc7ccc(C(C)(C)C)cc7c6c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C7CCCCC7)cc1c53)sc1ccc(C(C)(C)C)cc16)C(C)(C)CC4(C)C)C(C)(C)CCC2(C)C]

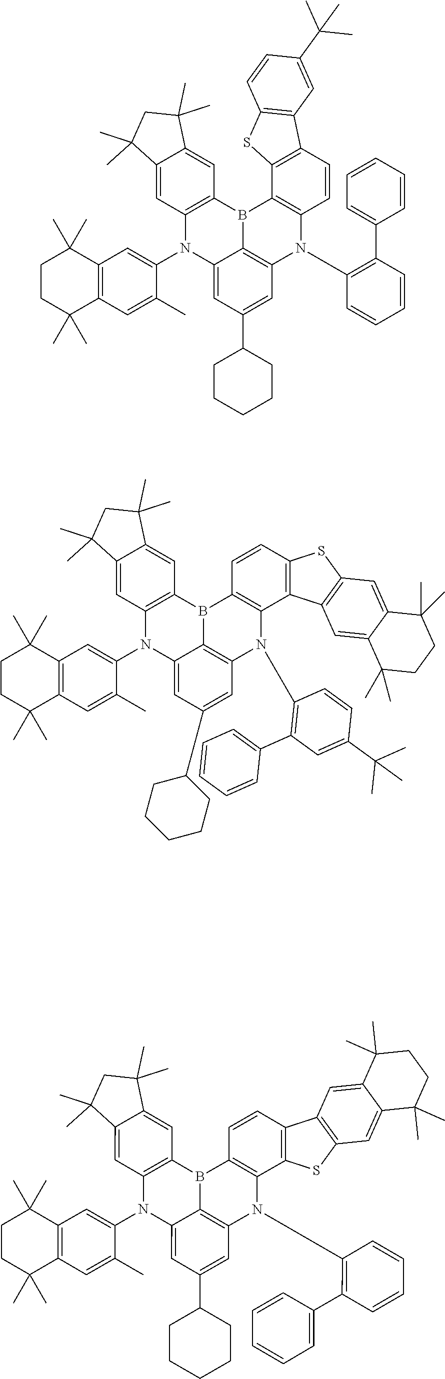 [SMILES: Cc1cc2c(cc1N1c3cc4c(cc3B3c5c1cc(C1CCCCC1)cc5N(c1ccccc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5ccc6sc7cc8c(cc7c6c5N(Cc5ccc(C(C)(C)C)cc5-c5ccccc5)c5cc(CC6CCCCC6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5-c5ccccc5)c5cc(C6CCCCC6)cc1c53)C(C)(C)CC4(C)C)C(C)(C)CCC2(C)C]

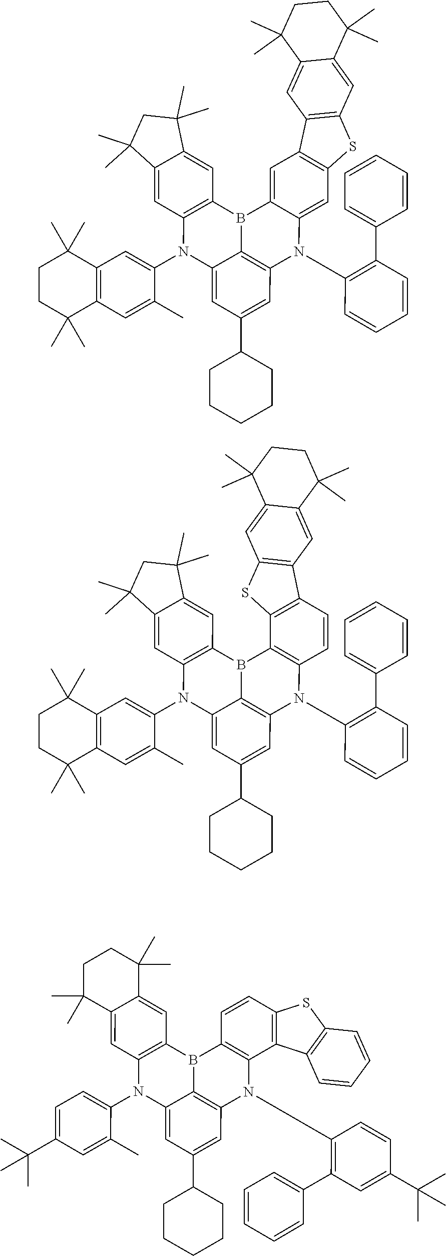

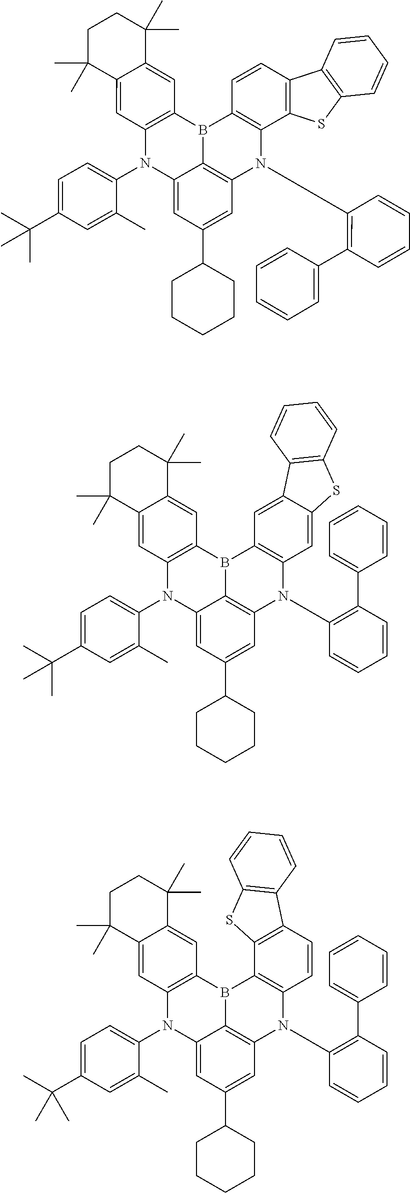 [SMILES: Cc1cc(C(C)(C)C)ccc1N1c2cc3c(cc2B2c4ccc5c(sc6ccccc65)c4N(c4ccccc4-c4ccccc4)c4cc(C5CCCCC5)cc1c42)C(C)(C)CCC3(C)C ; Cc1cc(C(C)(C)C)ccc1N1c2cc3c(cc2B2c4cc5c(cc4N(c4ccccc4-c4ccccc4)c4cc(C6CCCCC6)cc1c42)sc1ccccc15)C(C)(C)CCC3(C)C ; Cc1cc(C(C)(C)C)ccc1N1c2cc3c(cc2B2c4c1cc(C1CCCCC1)cc4N(c1ccccc1-c1ccccc1)c1ccc4c(sc5ccccc54)c12)C(C)(C)CCC3(C)C]

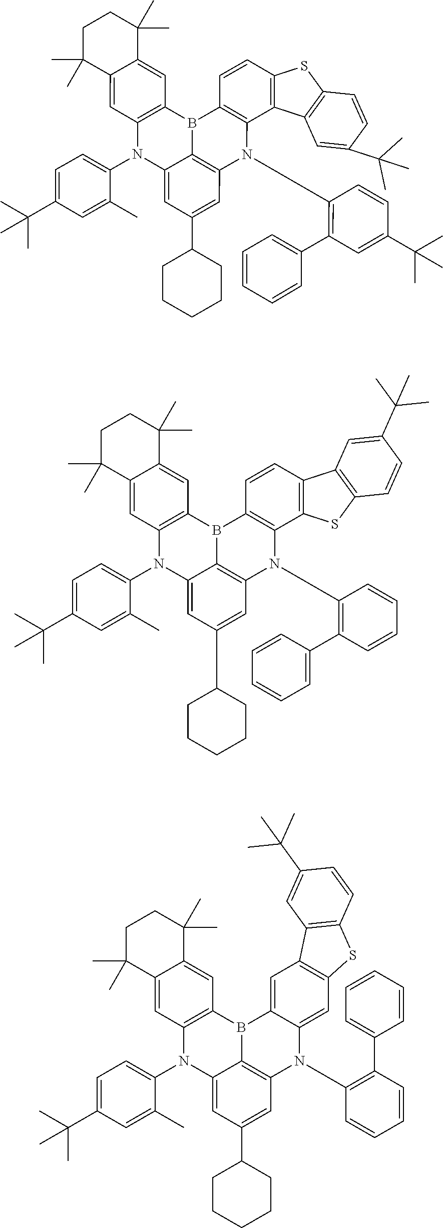

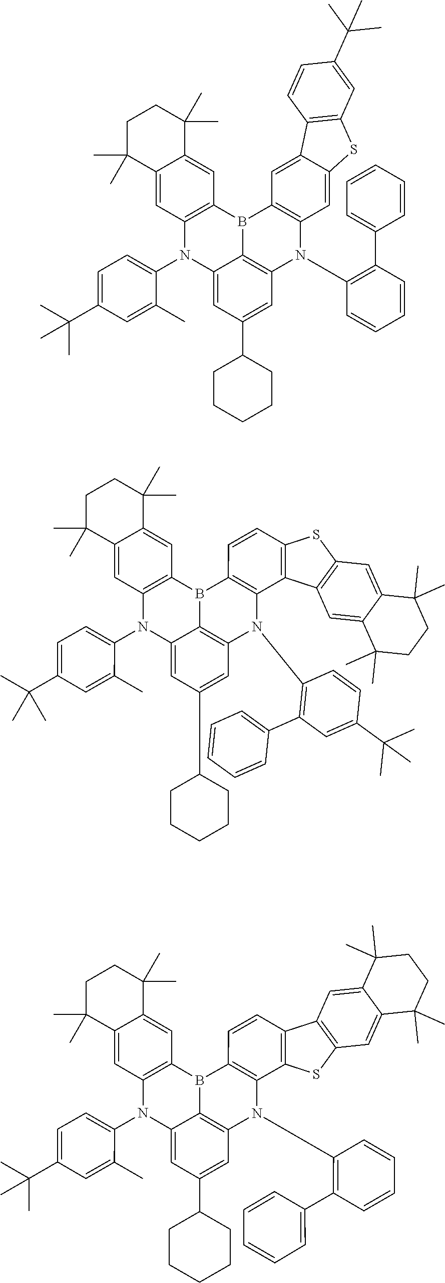

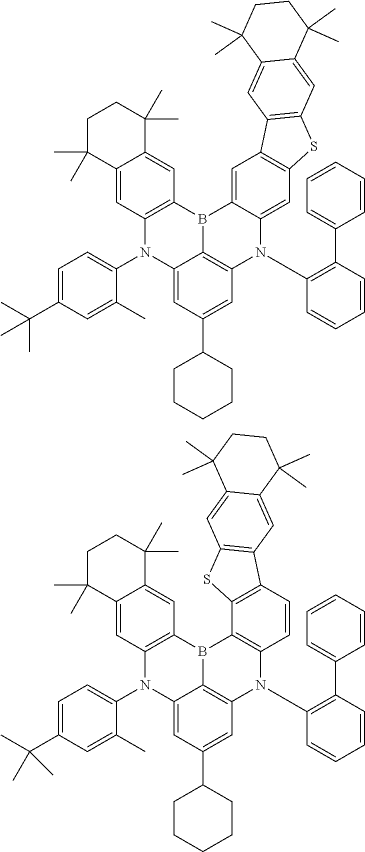

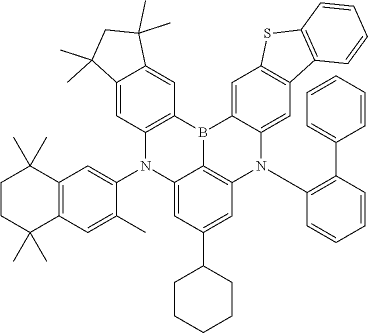 [SMILES: Cc1cc2c(cc1N1c3cc4c(cc3B3c5cc6sc7ccccc7c6cc5N(c5ccccc5-c5ccccc5)c5cc(C6CCCCC6)cc1c53)C(C)(C)CC4(C)C)C(C)(C)CCC2(C)C]

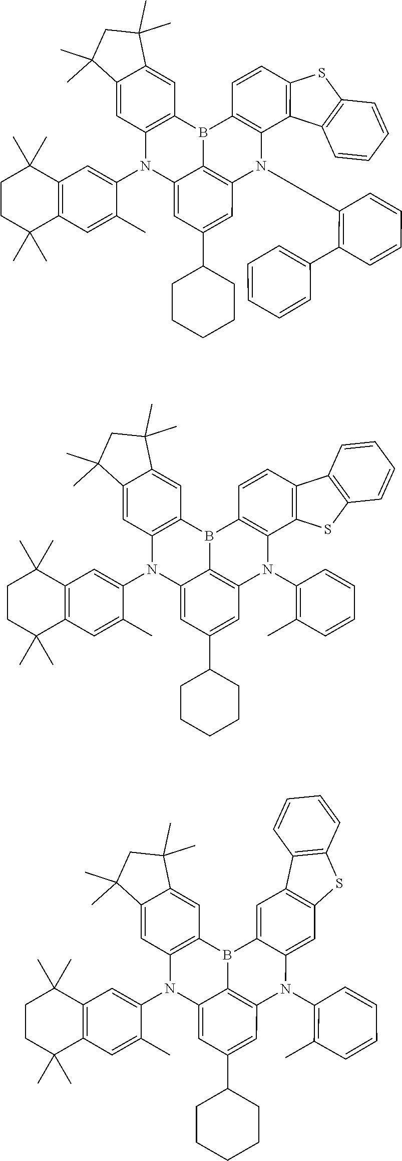 [SMILES: Cc1cc2c(cc1N1c3cc4c(cc3B3c5ccc6sc7ccccc7c6c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5C)c5cc(C6CCCCC6)cc1c53)C(C)(C)CC4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(C5CCCCC5)cc1c32)C(C)(C)CC4(C)C]

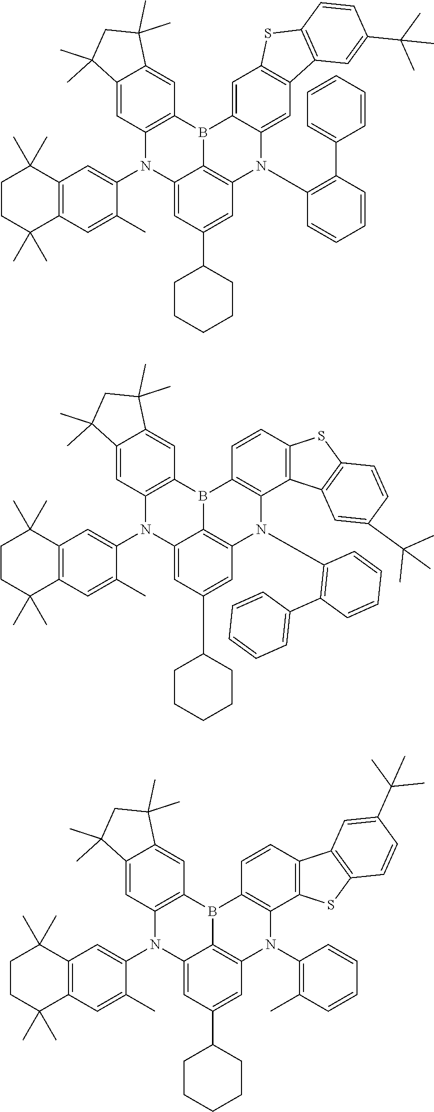 [SMILES: Cc1cc2c(cc1N1c3cc4c(cc3B3c5cc6sc7ccc(C(C)(C)C)cc7c6cc5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(C6CCCCC6)cc1c53)C(C)(C)CC4(C)C)C(C)(C)CCC2(C)C]

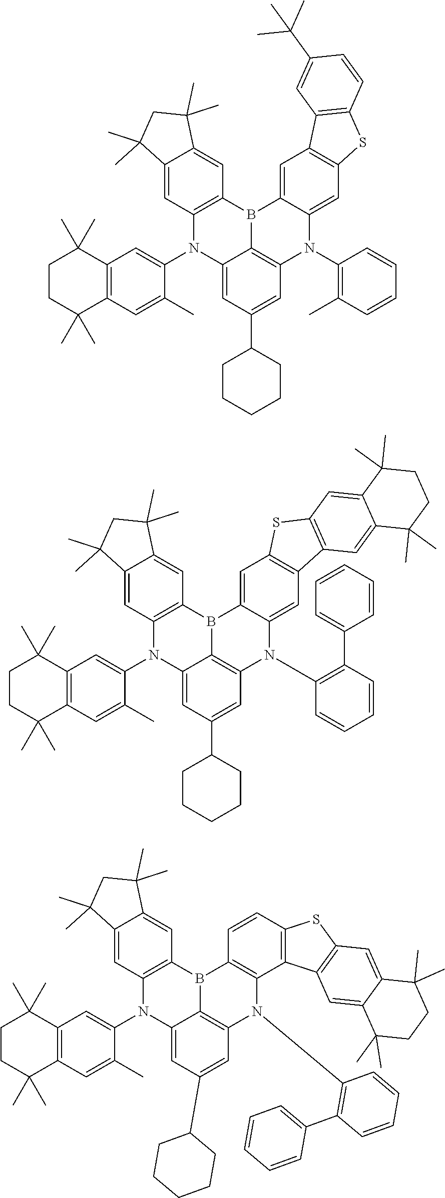

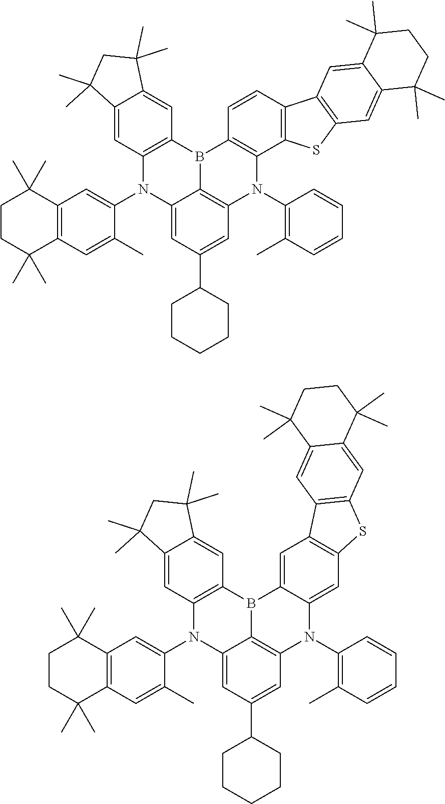 [SMILES: Cc1cc2c(cc1N1c3cc4c(cc3B3c5ccc6c(sc7cc8c(cc76)C(C)(C)CCC8(C)C)c5N(c5ccccc5C)c5cc(C6CCCCC6)cc1c53)C(C)(C)CC4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(C6CCCCC6)cc1c32)C(C)(C)CC4(C)C)C(C)(C)CCC5(C)C]

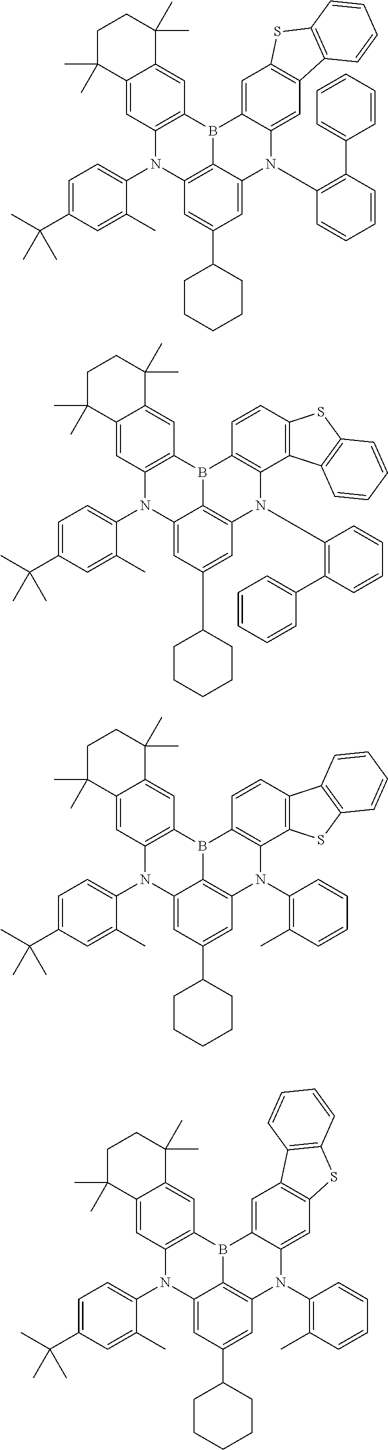

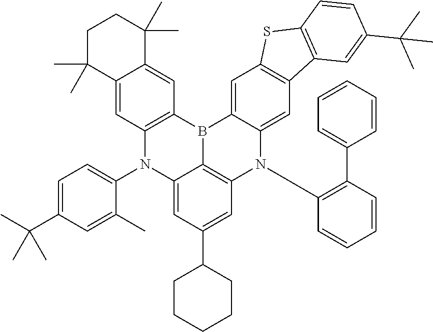 [SMILES: Cc1cc(C(C)(C)C)ccc1N1c2cc3c(cc2B2c4cc5sc6ccc(C(C)(C)C)cc6c5cc4N(c4ccccc4-c4ccccc4)c4cc(C5CCCCC5)cc1c42)C(C)(C)CCC3(C)C]

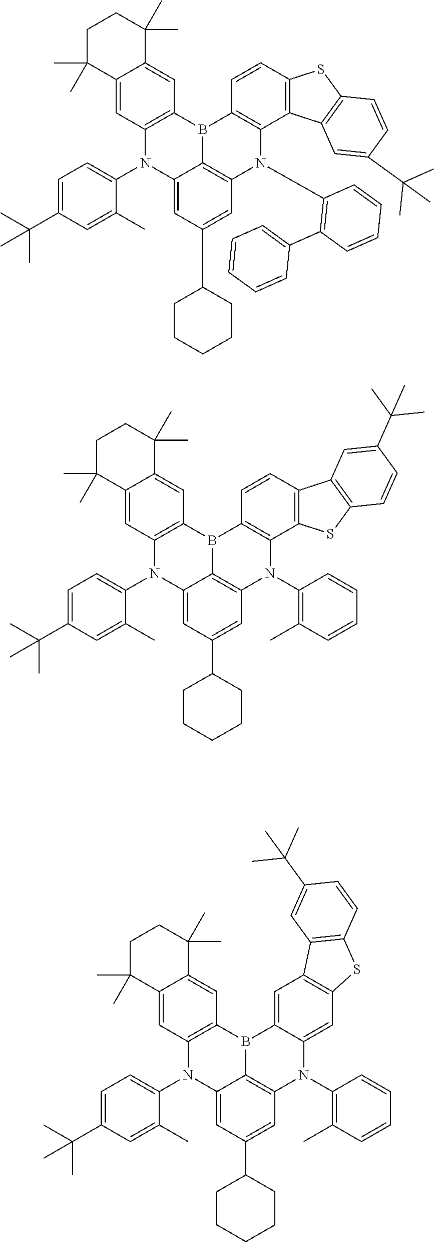

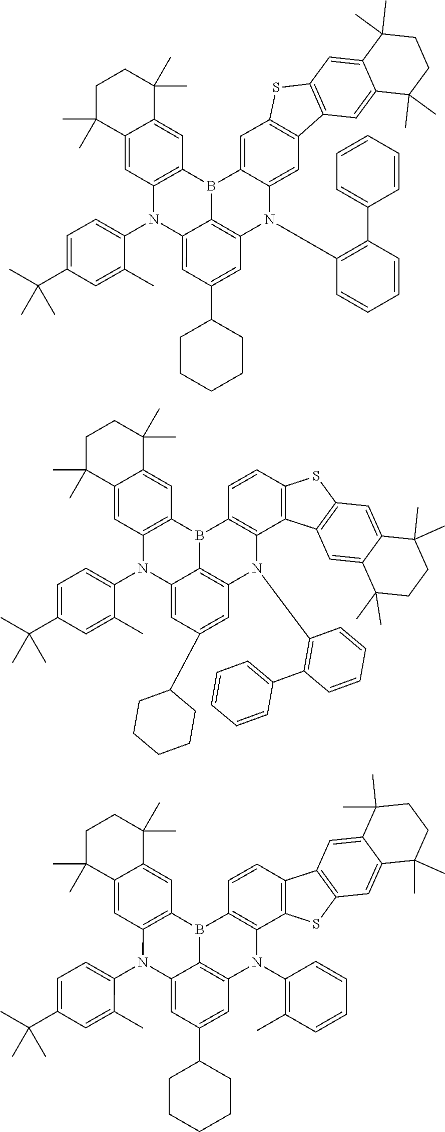

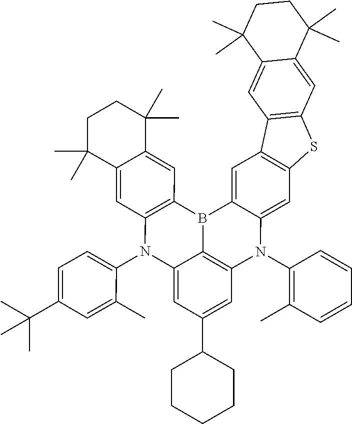 [SMILES: Cc1cc(C(C)(C)C)ccc1N1c2cc3c(cc2B2c4cc5c(cc4N(c4ccccc4C)c4cc(C6CCCCC6)cc1c42)sc1cc2c(cc15)C(C)(C)CCC2(C)C)C(C)(C)CCC3(C)C]

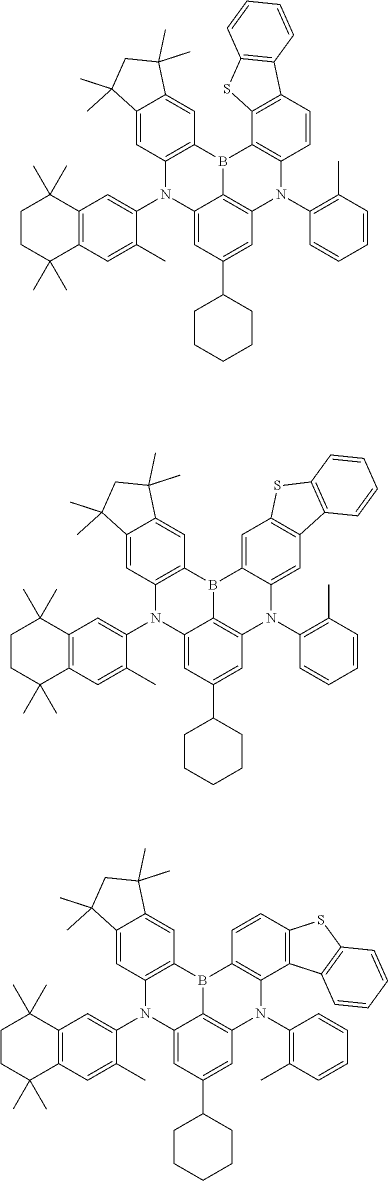 [SMILES: Cc1cc2c(cc1N1c3cc4c(cc3B3c5c1cc(C1CCCCC1)cc5N(c1ccccc1C)c1ccc5c(sc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)CC5(C)C)sc1ccccc13 ; Cc1cc2c(cc1N1c3cc4c(cc3B3c5ccc6sc7ccccc7c6c5N(c5ccccc5C)c5cc(C6CCCCC6)cc1c53)C(C)(C)CC4(C)C)C(C)(C)CCC2(C)C]

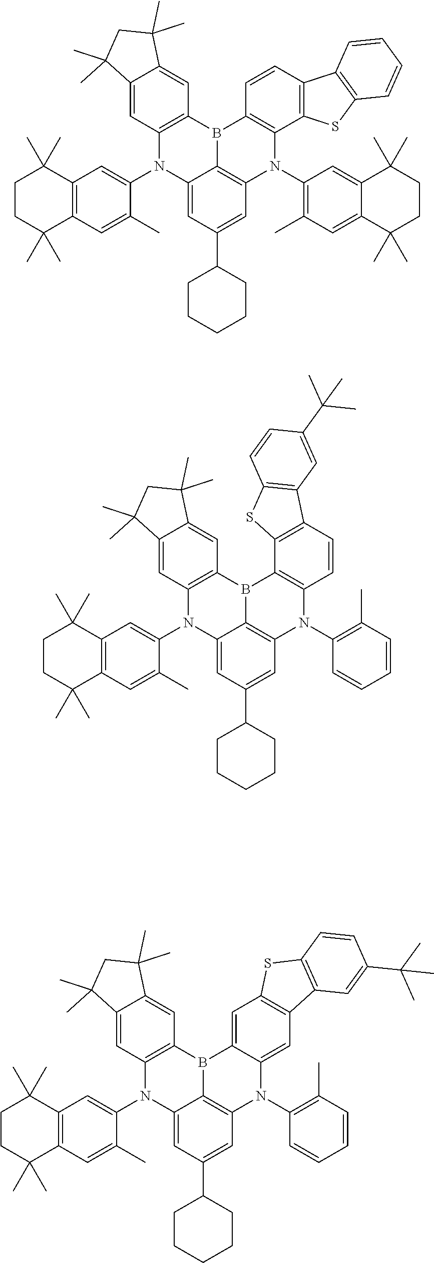 [SMILES: Cc1cc2c(cc1N1c3cc4c(cc3B3c5ccc6c(sc7ccccc76)c5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5c1cc(C1CCCCC1)cc5N(c1ccccc1C)c1ccc5c(sc6ccc(C(C)(C)C)cc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)CC5(C)C)sc1ccc(C(C)(C)C)cc13]

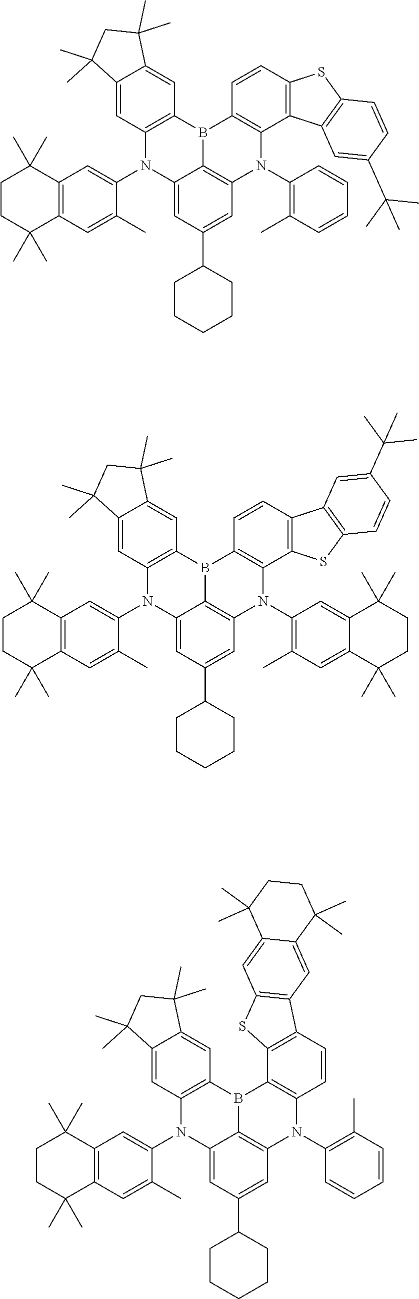 [SMILES: Cc1cc2c(cc1N1c3cc4c(cc3B3c5ccc6sc7ccc(C(C)(C)C)cc7c6c5N(c5ccccc5C)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5c1cc(C1CCCCC1)cc5N(c1ccccc1C)c1ccc5c(sc6cc7c(cc65)C(C)(C)CCC7(C)C)c13)C(C)(C)CC4(C)C)C(C)(C)CCC2(C)C]

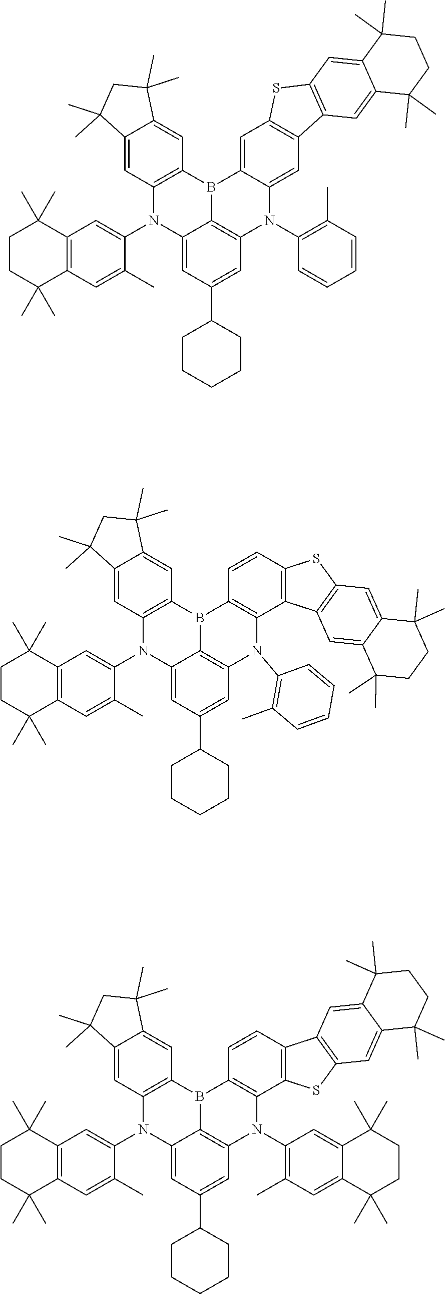 [SMILES: Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)CC5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(C6CCCCC6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(C6CCCCC6)cc1c53)C(C)(C)CC4(C)C)C(C)(C)CCC2(C)C]

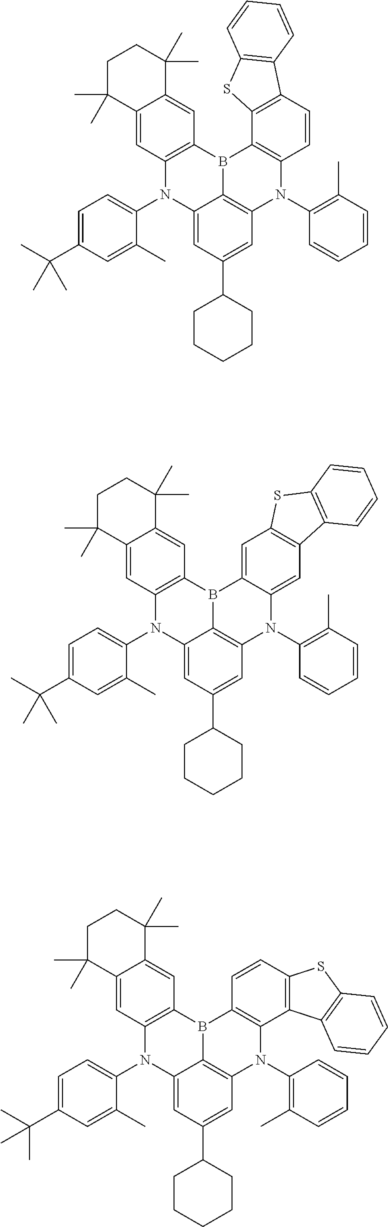 [SMILES: Cc1cc(C(C)(C)C)ccc1N1c2cc3c(cc2B2c4c1cc(C1CCCCC1)cc4N(c1ccccc1C)c1ccc4c(sc5ccccc54)c12)C(C)(C)CCC3(C)C ; Cc1cc(C(C)(C)C)ccc1N1c2cc3c(cc2B2c4cc5sc6ccccc6c5cc4N(c4ccccc4C)c4cc(C5CCCCC5)cc1c42)C(C)(C)CCC3(C)C ; Cc1cc(C(C)(C)C)ccc1N1c2cc3c(cc2B2c4ccc5sc6ccccc6c5c4N(c4ccccc4C)c4cc(C5CCCCC5)cc1c42)C(C)(C)CCC3(C)C]

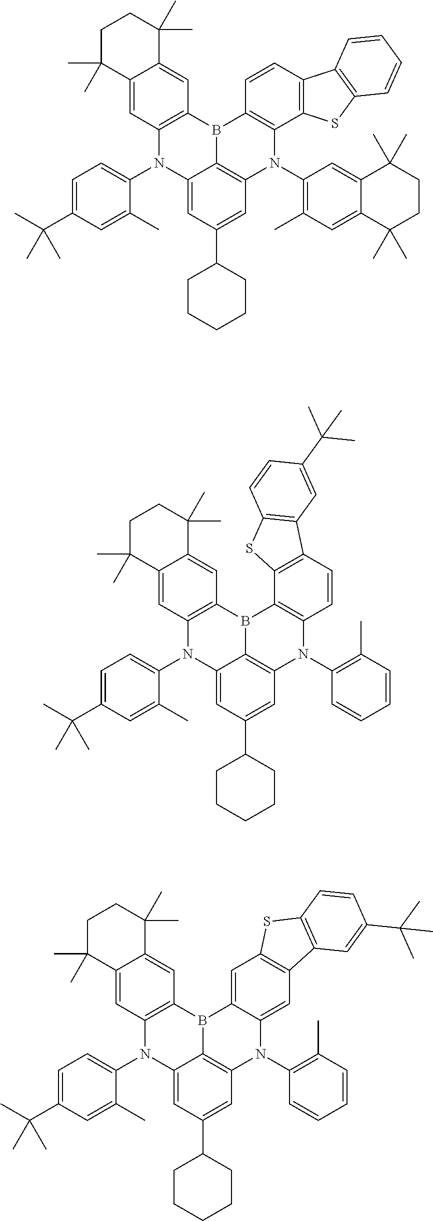 [SMILES: Cc1cc(C(C)(C)C)ccc1N1c2cc3c(cc2B2c4ccc5c(sc6ccccc65)c4N(c4cc5c(cc4C)C(C)(C)CCC5(C)C)c4cc(C5CCCCC5)cc1c42)C(C)(C)CCC3(C)C ; Cc1cc(C(C)(C)C)ccc1N1c2cc3c(cc2B2c4c1cc(C1CCCCC1)cc4N(c1ccccc1C)c1ccc4c(sc5ccc(C(C)(C)C)cc54)c12)C(C)(C)CCC3(C)C ; Cc1cc(C(C)(C)C)ccc1N1c2cc3c(cc2B2c4cc5sc6ccc(C(C)(C)C)cc6c5cc4N(c4ccccc4C)c4cc(C5CCCCC5)cc1c42)C(C)(C)CCC3(C)C]

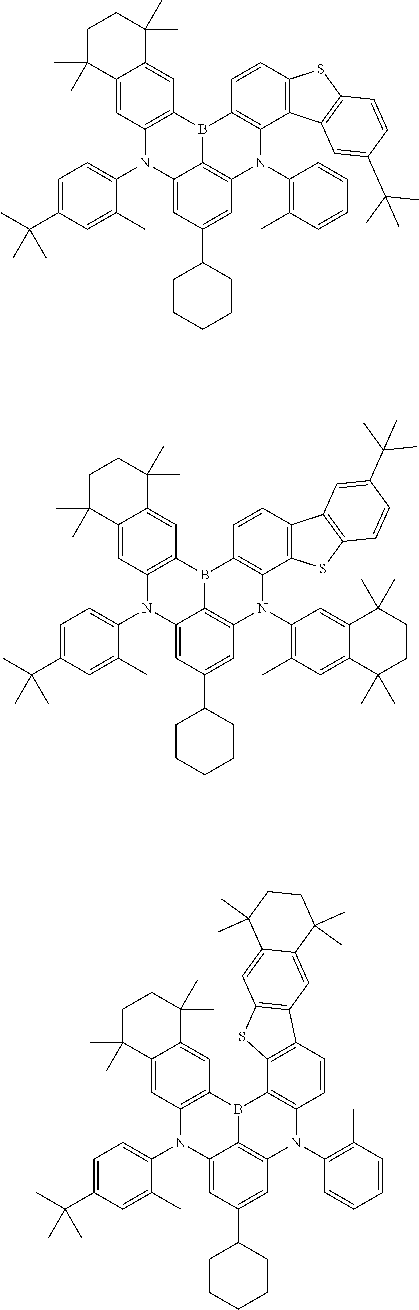

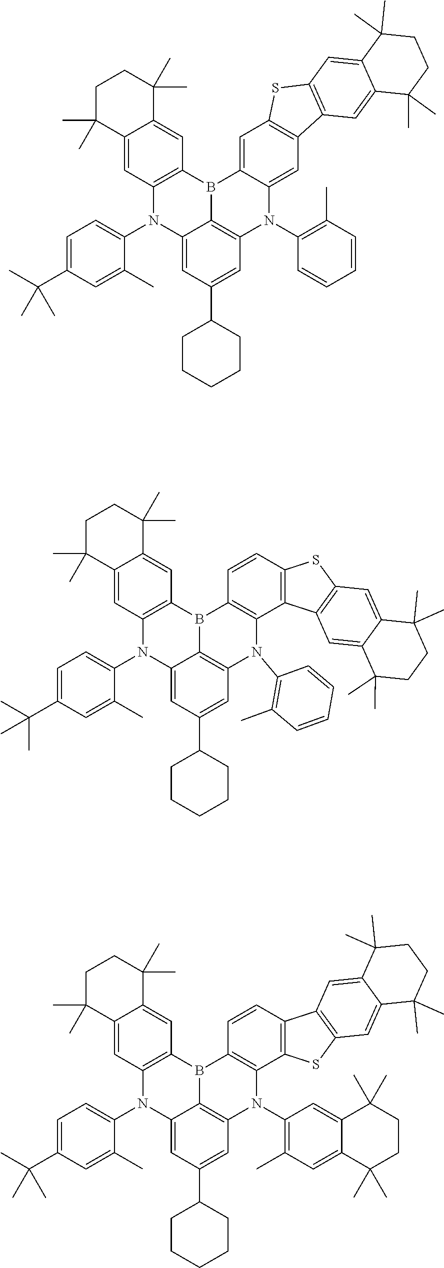

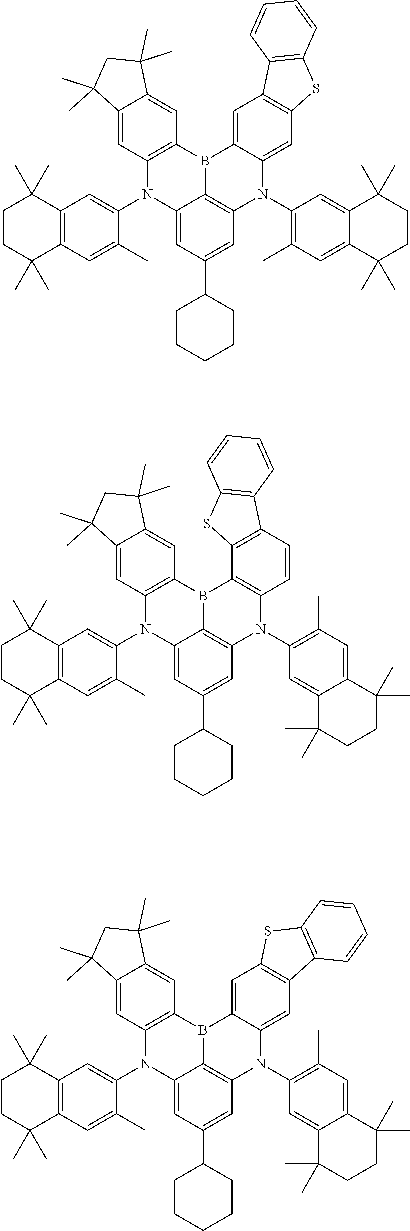 [SMILES: Cc1cc2c(cc1N1c3cc4c(cc3B3c5cc6c(cc5N(c5cc7c(cc5C)C(C)(C)CCC7(C)C)c5cc(C7CCCCC7)cc1c53)sc1ccccc16)C(C)(C)CC4(C)C)C(C)(C)CCC2(C)C ; Cc1cc2c(cc1N1c3cc4c(cc3B3c5c1cc(C1CCCCC1)cc5N(c1cc5c(cc1C)C(C)(C)CCC5(C)C)c1ccc5c(sc6ccccc65)c13)C(C)(C)CC4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(C6CCCCC6)cc1c53)C(C)(C)CC4(C)C)C(C)(C)CCC2(C)C]

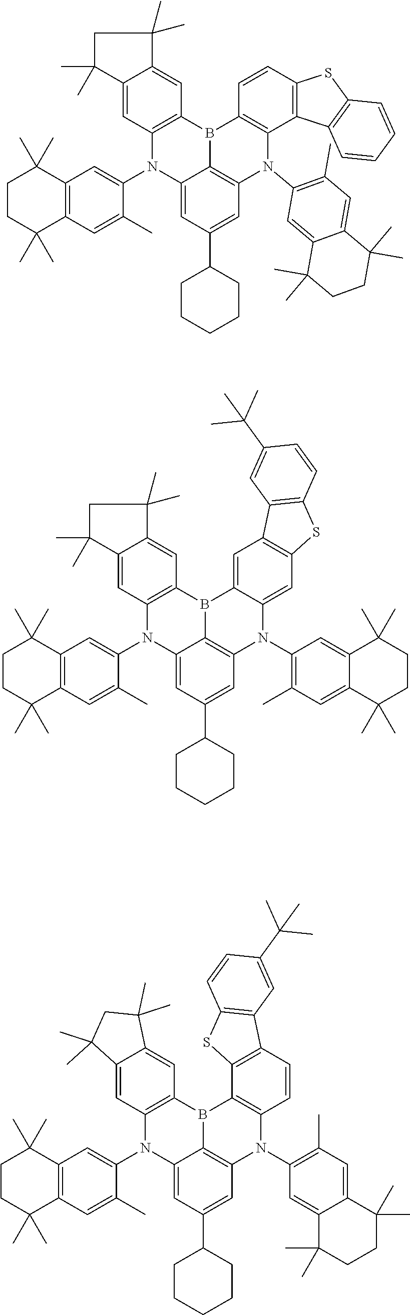 [SMILES: Cc1cc2c(cc1N1c3cc4c(cc3B3c5ccc6sc7ccccc7c6c5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C7CCCCC7)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(C1CCCCC1)cc5N(c1cc5c(cc1C)C(C)(C)CCC5(C)C)c1ccc5c(sc6ccc(C(C)(C)C)cc65)c13)C(C)(C)CC4(C)C)C(C)(C)CCC2(C)C]

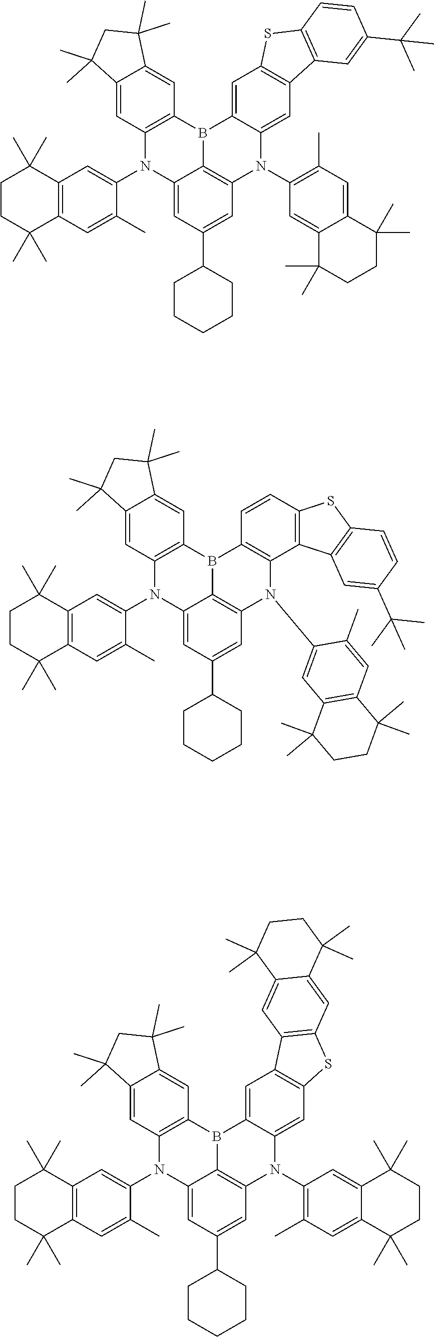 [SMILES: Cc1cc2c(cc1N1c3cc4c(cc3B3c5cc6sc7ccc(C(C)(C)C)cc7c6cc5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C7CCCCC7)cc1c53)sc1cc3c(cc16)C(C)(C)CCC3(C)C)C(C)(C)CC4(C)C)C(C)(C)CCC2(C)C]

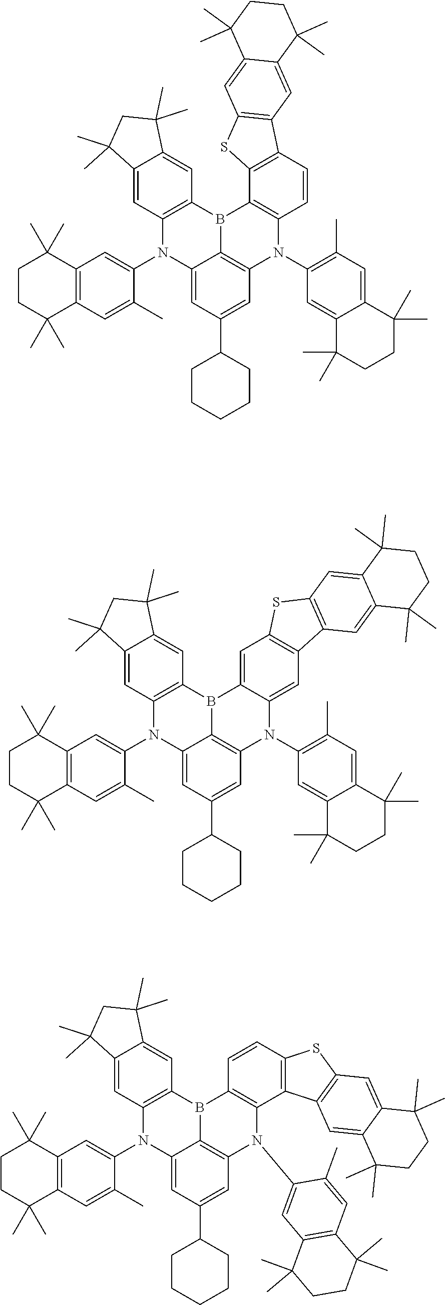

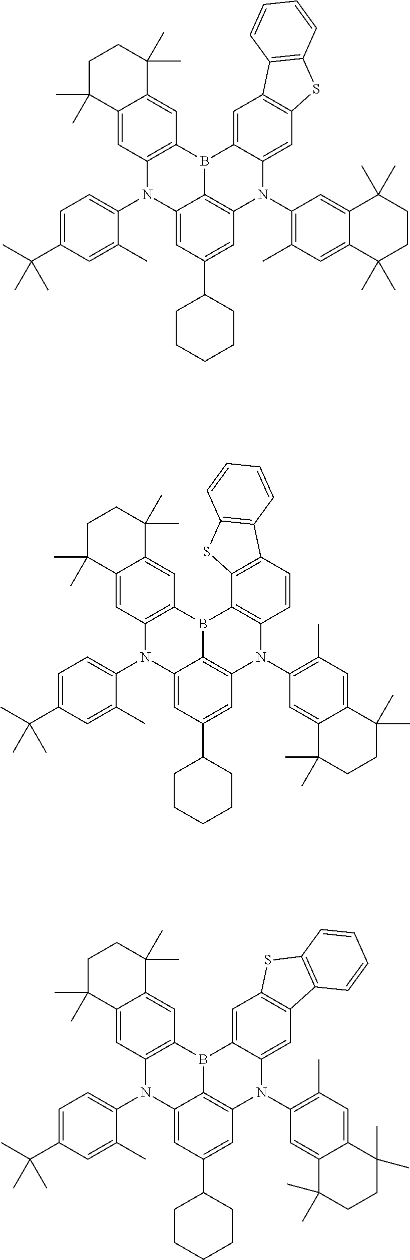

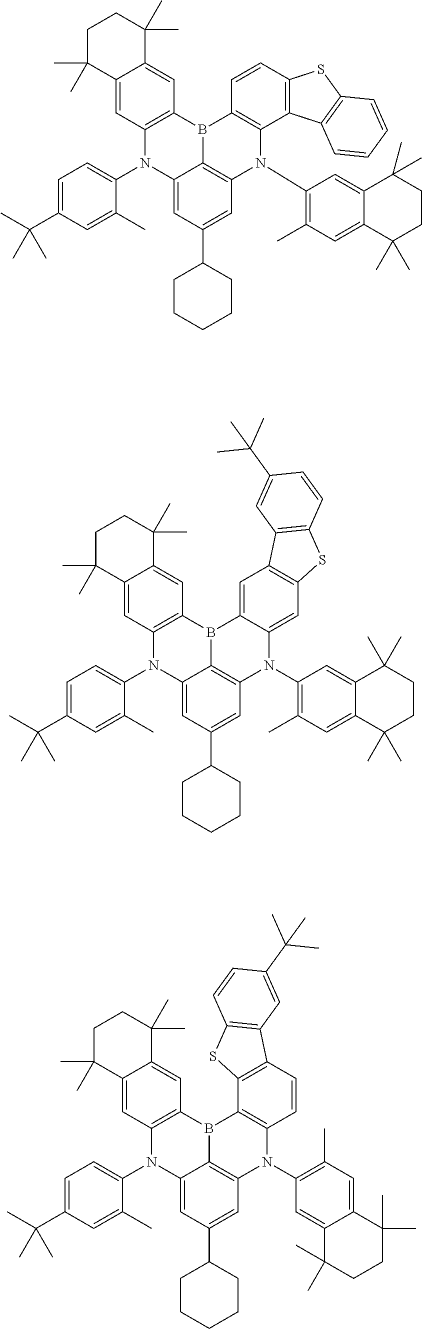

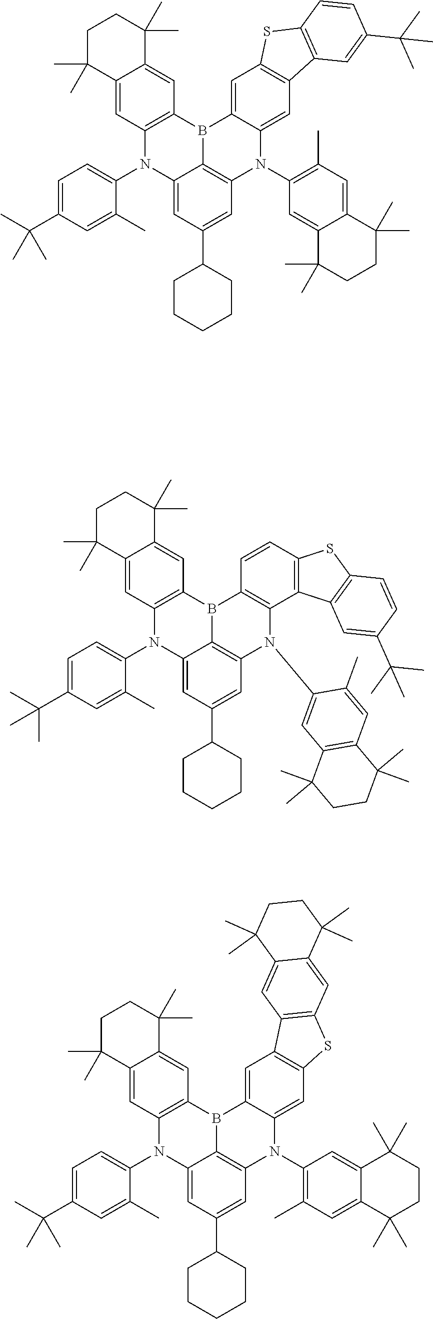

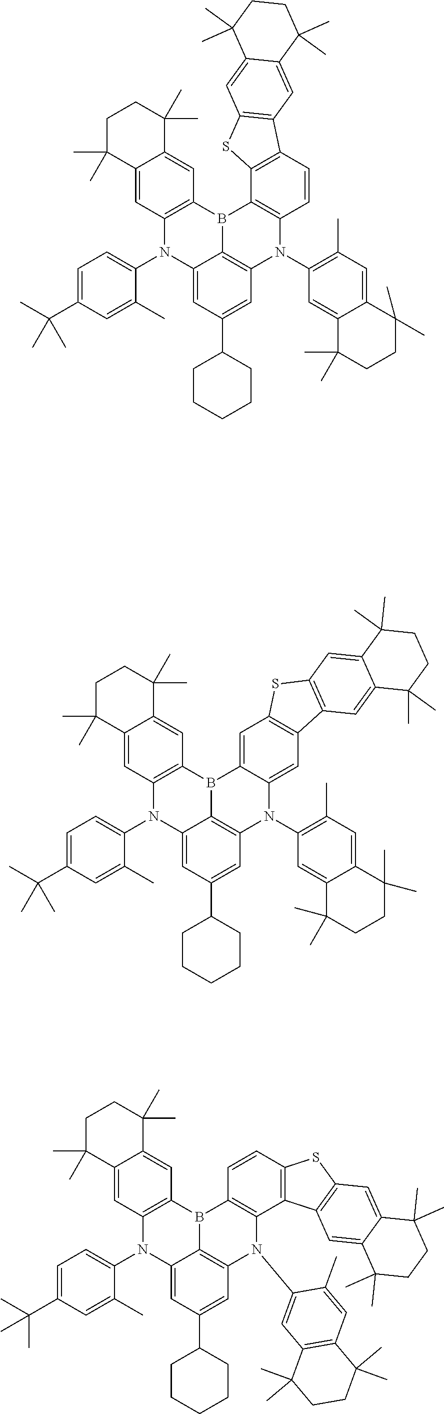

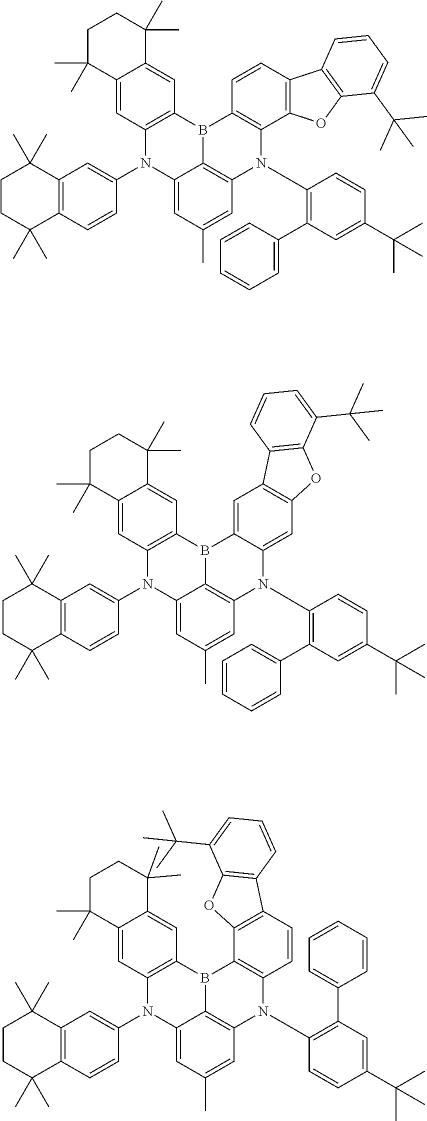 [SMILES: Cc1cc2c3c(c1)N(c1ccc(C(C)(C)C)cc1-c1ccccc1)c1c(ccc4c1oc1c(C(C)(C)C)cccc14)B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4oc5c(C(C)(C)C)cccc5c4cc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1ccc4c(oc5c(C(C)(C)C)cccc54)c1B3c1cc3c(cc1N2c1ccc2c(c1)C(C)(C)CCC2(C)C)C(C)(C)CCC3(C)C]

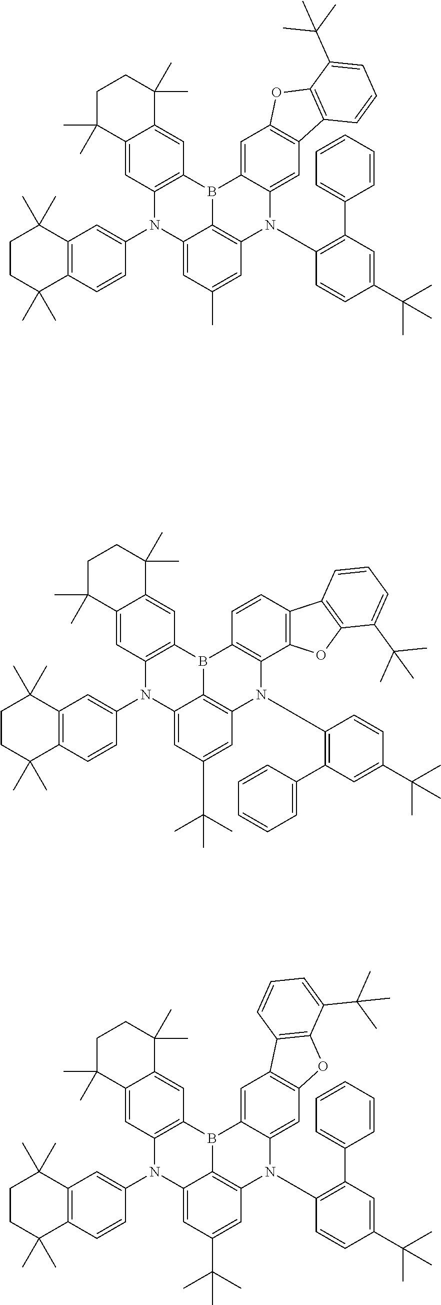 [SMILES: Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1c(C(C)(C)C)cccc14 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3ccc4c(oc5c(C(C)(C)C)cccc54)c32)c(-c2ccccc2)c1 ; CC(C)(C)c1ccc(N2c3cc4oc5c(C(C)(C)C)cccc5c4cc3B3c4cc5c(cc4N(c4ccc6c(c4)C(C)(C)CCC6(C)C)c4cc(C(C)(C)C)cc2c43)C(C)(C)CCC5(C)C)c(-c2ccccc2)c1]

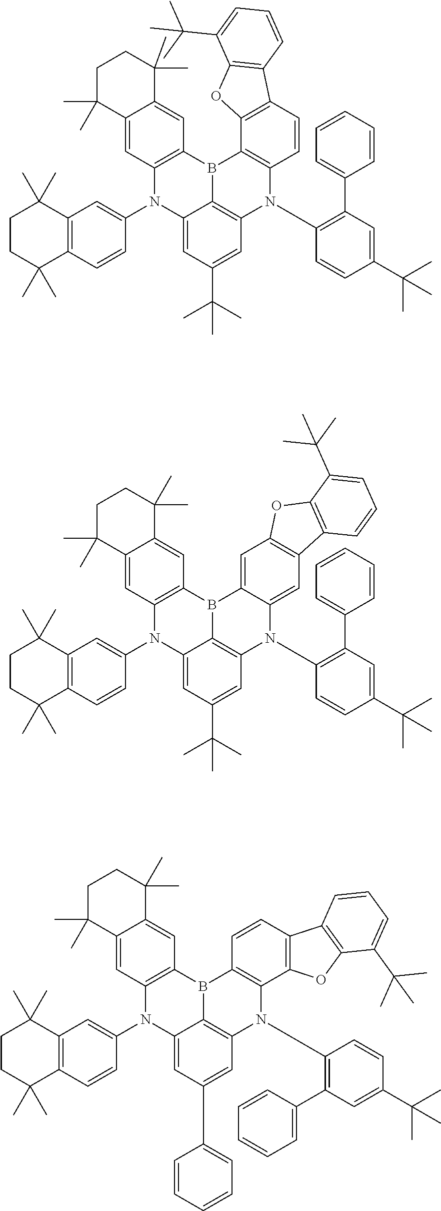 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3c2ccc2c3oc3c(C(C)(C)C)cccc32)c(-c2ccccc2)c1 ; CC(C)(C)c1ccc(N2c3cc4c(cc3B3c5cc6c(cc5N(c5ccc7c(c5)C(C)(C)CCC7(C)C)c5cc(C(C)(C)C)cc2c53)C(C)(C)CCC6(C)C)oc2c(C(C)(C)C)cccc24)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(oc5c(C(C)(C)C)cccc54)c32)c(-c2ccccc2)c1]

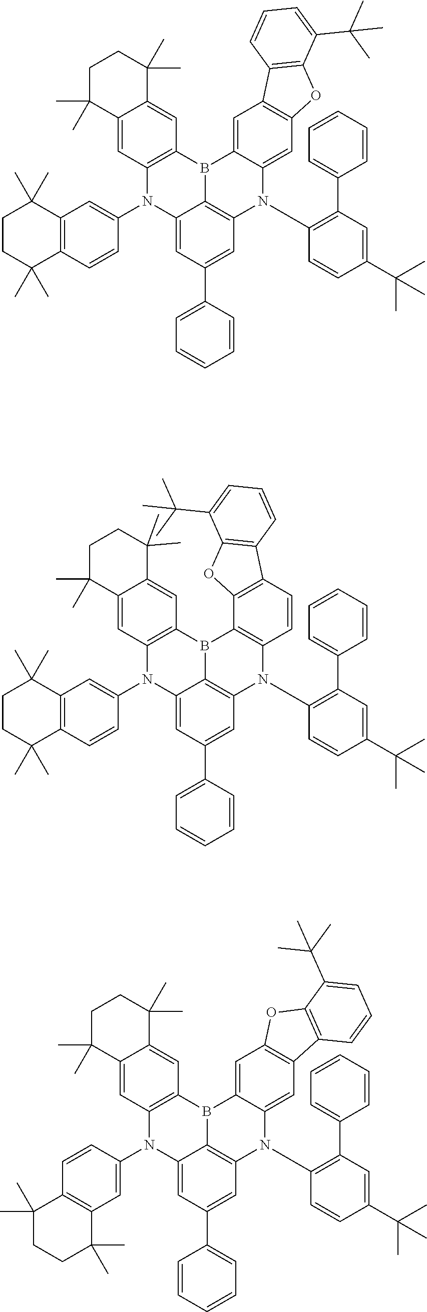

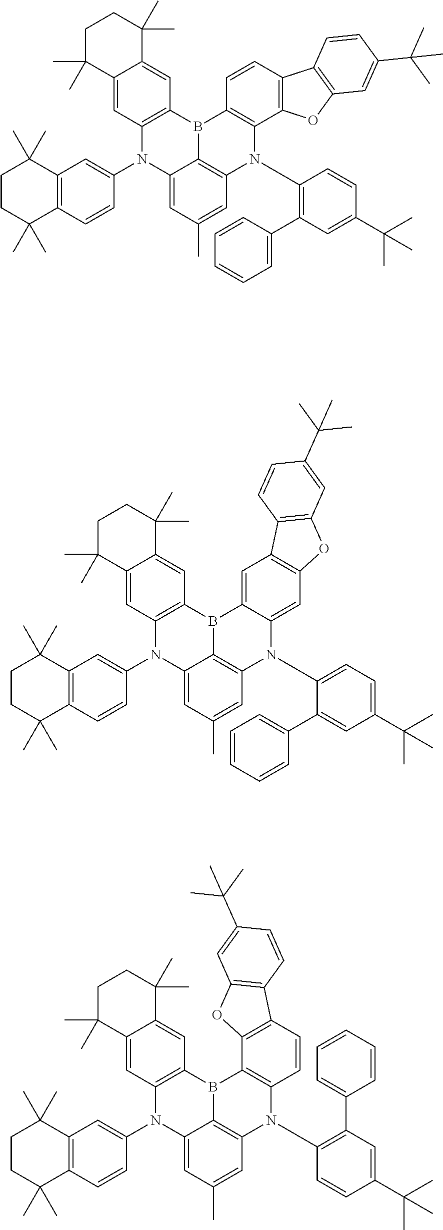 [SMILES: Cc1cc2c3c(c1)N(c1ccc(C(C)(C)C)cc1-c1ccccc1)c1c(ccc4c1oc1cc(C(C)(C)C)ccc14)B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4oc5cc(C(C)(C)C)ccc5c4cc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1ccc4c(oc5cc(C(C)(C)C)ccc54)c1B3c1cc3c(cc1N2c1ccc2c(c1)C(C)(C)CCC2(C)C)C(C)(C)CCC3(C)C]

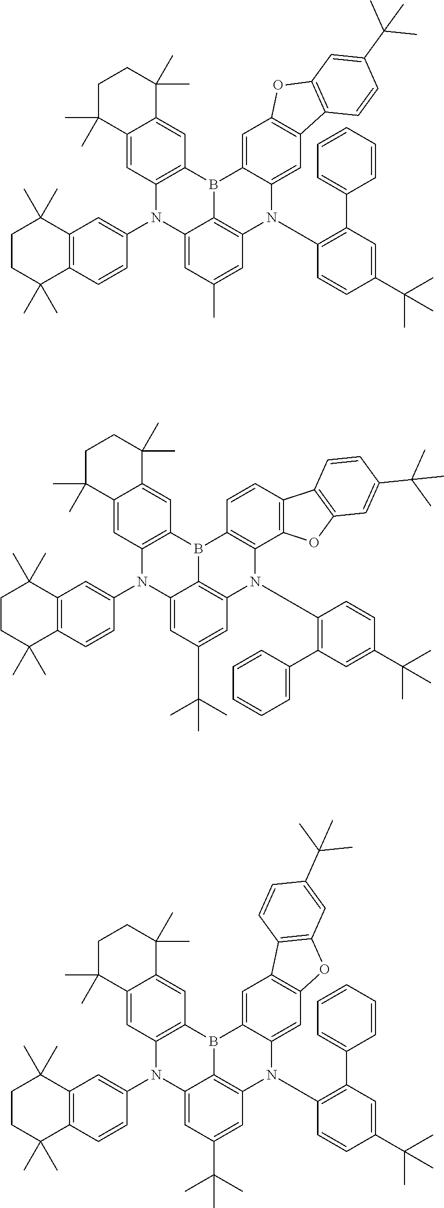 [SMILES: Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1cc(C(C)(C)C)ccc14 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3ccc4c(oc5cc(C(C)(C)C)ccc54)c32)c(-c2ccccc2)c1 ; CC(C)(C)c1ccc(N2c3cc4oc5cc(C(C)(C)C)ccc5c4cc3B3c4cc5c(cc4N(c4ccc6c(c4)C(C)(C)CCC6(C)C)c4cc(C(C)(C)C)cc2c43)C(C)(C)CCC5(C)C)c(-c2ccccc2)c1]

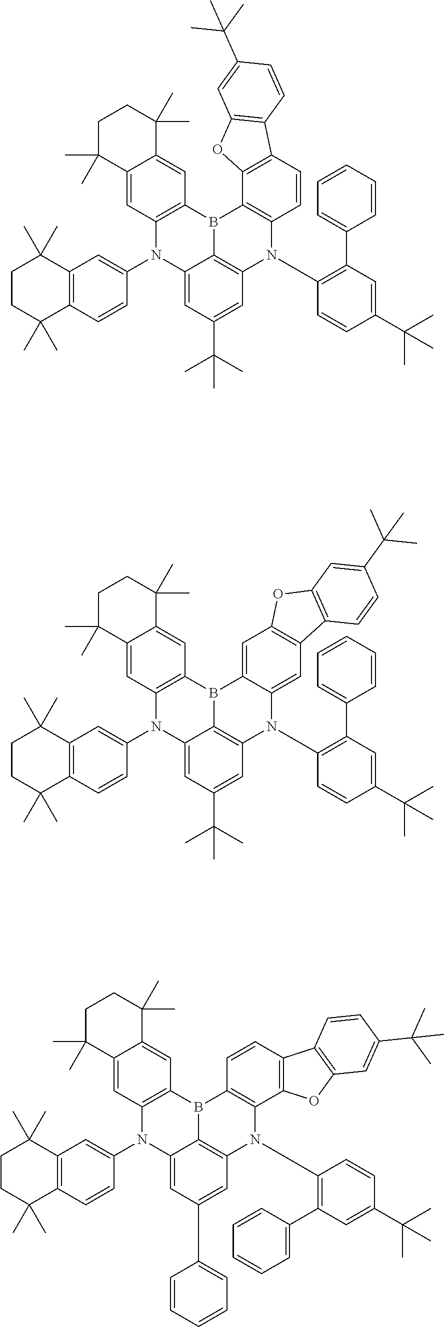 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3c2ccc2c3oc3cc(C(C)(C)C)ccc32)c(-c2ccccc2)c1 ; CC(C)(C)c1ccc(N2c3cc4c(cc3B3c5cc6c(cc5N(c5ccc7c(c5)C(C)(C)CCC7(C)C)c5cc(C(C)(C)C)cc2c53)C(C)(C)CCC6(C)C)oc2cc(C(C)(C)C)ccc24)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(oc5cc(C(C)(C)C)ccc54)c32)c(-c2ccccc2)c1]

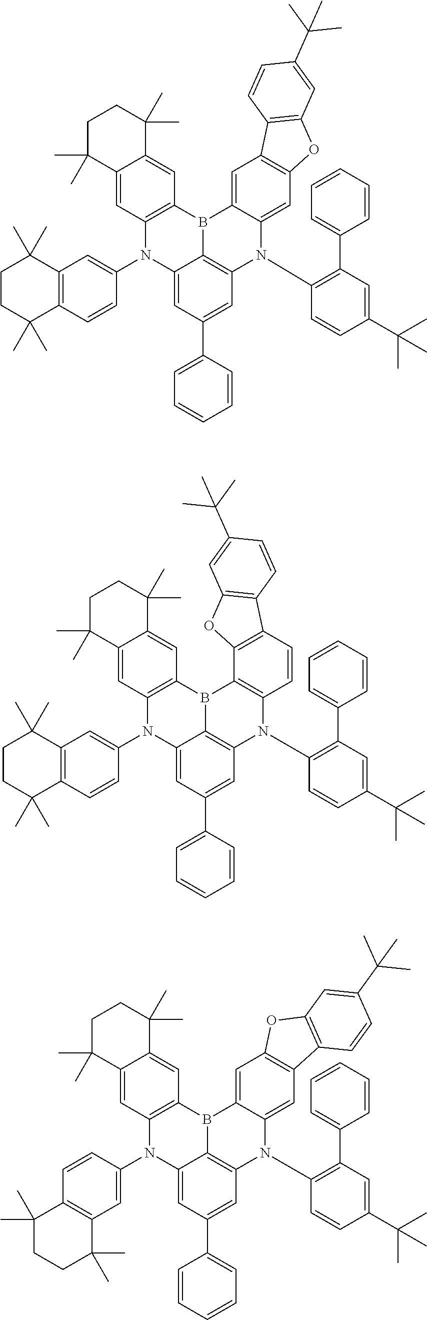

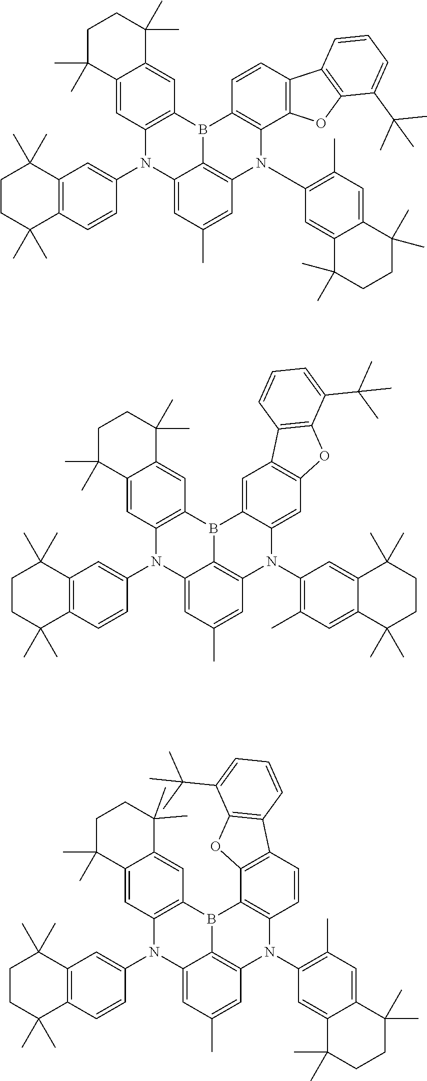 [SMILES: Cc1cc2c3c(c1)N(c1cc4c(cc1C)C(C)(C)CCC4(C)C)c1c(ccc4c1oc1c(C(C)(C)C)cccc14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc4oc5c(C(C)(C)C)cccc5c4cc1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1ccc4c(oc5c(C(C)(C)C)cccc54)c1B3c1cc3c(cc1N2c1ccc2c(c1)C(C)(C)CCC2(C)C)C(C)(C)CCC3(C)C]

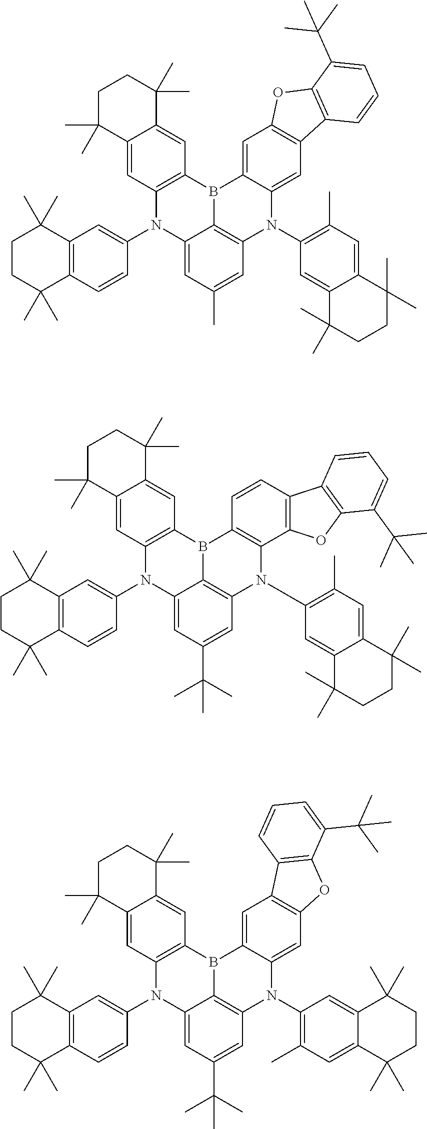 [SMILES: Cc1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1c(C(C)(C)C)cccc14 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5c(C(C)(C)C)cccc54)c31)C(C)(C)CCC2(C)C ; Cc1cc2c(cc1N1c3cc4oc5c(C(C)(C)C)cccc5c4cc3B3c4cc5c(cc4N(c4ccc6c(c4)C(C)(C)CCC6(C)C)c4cc(C(C)(C)C)cc1c43)C(C)(C)CCC5(C)C)C(C)(C)CCC2(C)C]

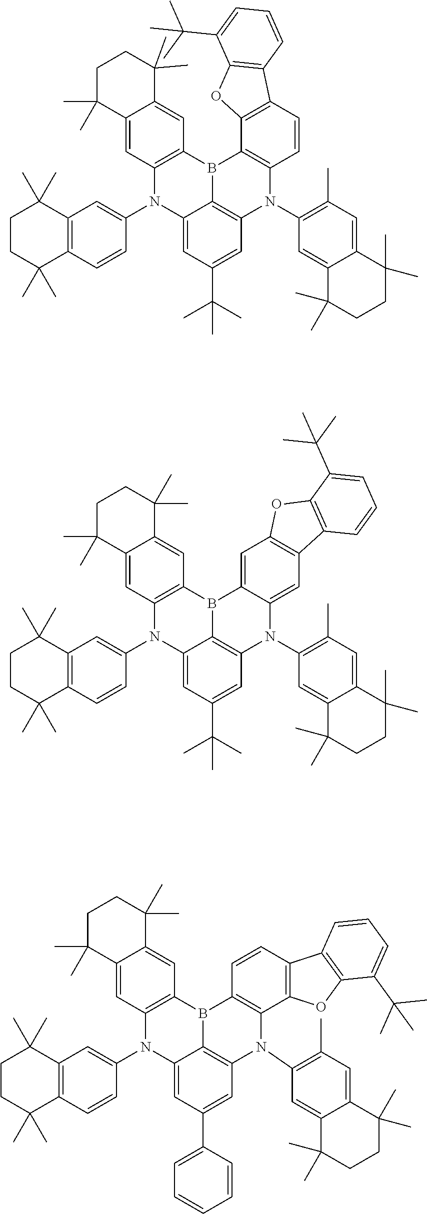 [SMILES: Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3c1ccc1c3oc3c(C(C)(C)C)cccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(C(C)(C)C)cc1c53)C(C)(C)CCC6(C)C)oc1c(C(C)(C)C)cccc14)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3ccc4c(oc5c(C(C)(C)C)cccc54)c31)C(C)(C)CCC2(C)C]

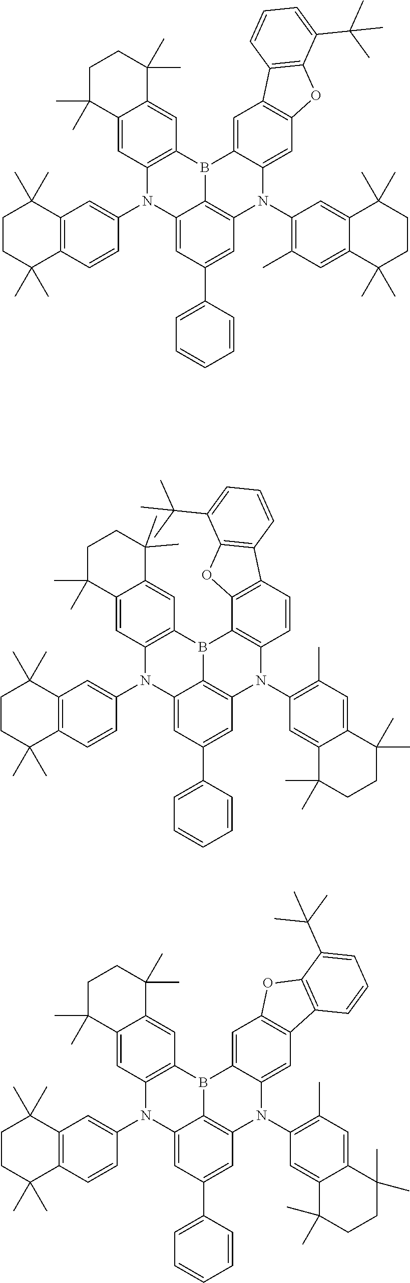 [SMILES: Cc1cc2c(cc1N1c3cc4oc5c(C(C)(C)C)cccc5c4cc3B3c4cc5c(cc4N(c4ccc6c(c4)C(C)(C)CCC6(C)C)c4cc(-c6ccccc6)cc1c43)C(C)(C)CCC5(C)C)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3c1ccc1c3oc3c(C(C)(C)C)cccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)oc1c(C(C)(C)C)cccc14)C(C)(C)CCC2(C)C]

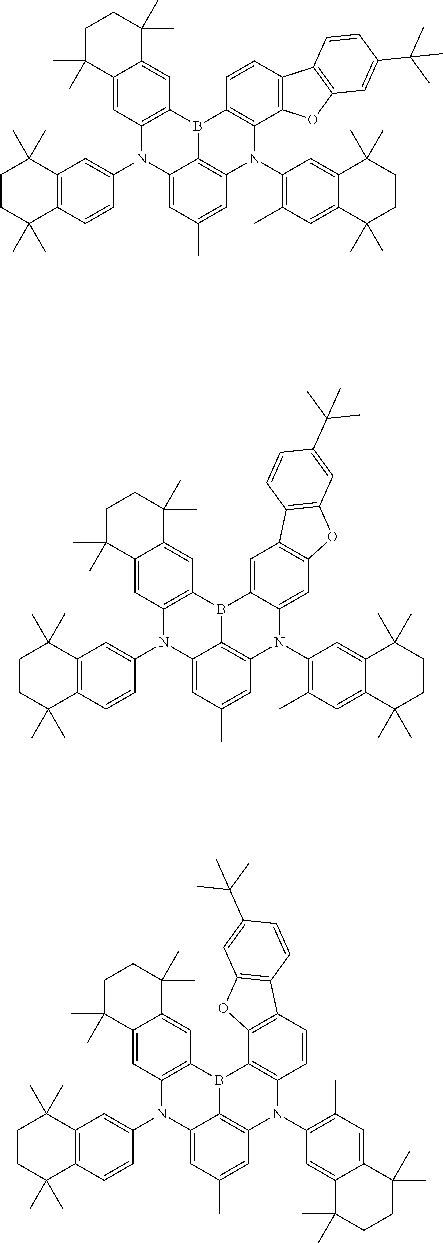 [SMILES: Cc1cc2c3c(c1)N(c1cc4c(cc1C)C(C)(C)CCC4(C)C)c1c(ccc4c1oc1cc(C(C)(C)C)ccc14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc4oc5cc(C(C)(C)C)ccc5c4cc1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1ccc4c(oc5cc(C(C)(C)C)ccc54)c1B3c1cc3c(cc1N2c1ccc2c(c1)C(C)(C)CCC2(C)C)C(C)(C)CCC3(C)C]

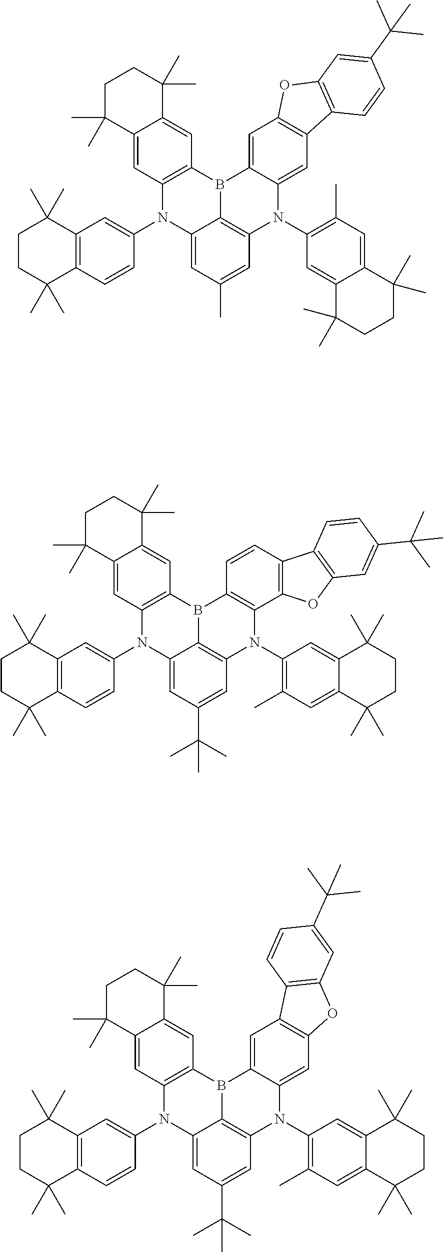 [SMILES: Cc1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1cc(C(C)(C)C)ccc14 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5cc(C(C)(C)C)ccc54)c31)C(C)(C)CCC2(C)C ; Cc1cc2c(cc1N1c3cc4oc5cc(C(C)(C)C)ccc5c4cc3B3c4cc5c(cc4N(c4ccc6c(c4)C(C)(C)CCC6(C)C)c4cc(C(C)(C)C)cc1c43)C(C)(C)CCC5(C)C)C(C)(C)CCC2(C)C]

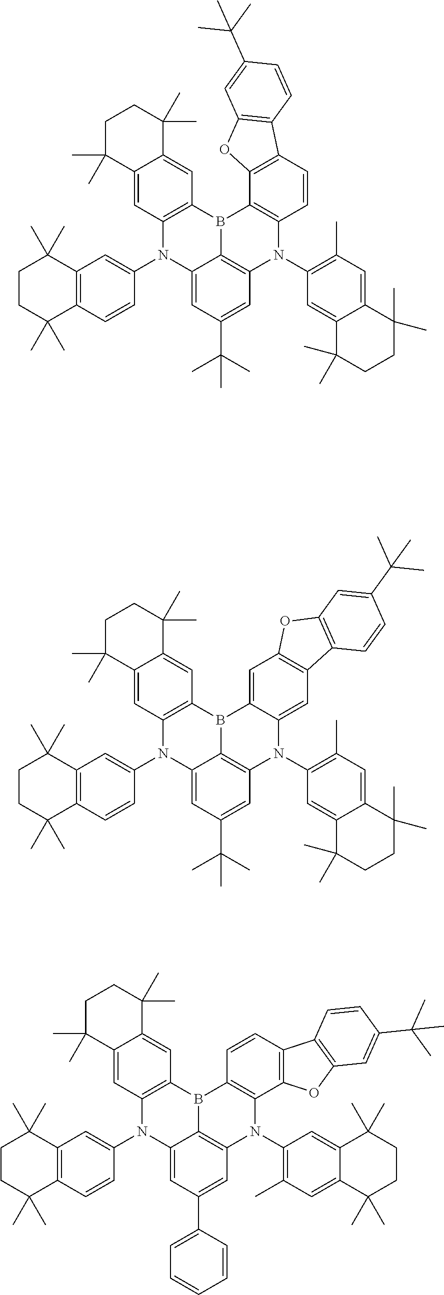 [SMILES: Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3c1ccc1c3oc3cc(C(C)(C)C)ccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(C(C)(C)C)cc1c53)C(C)(C)CCC6(C)C)oc1cc(C(C)(C)C)ccc14)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3ccc4c(oc5cc(C(C)(C)C)ccc54)c31)C(C)(C)CCC2(C)C]

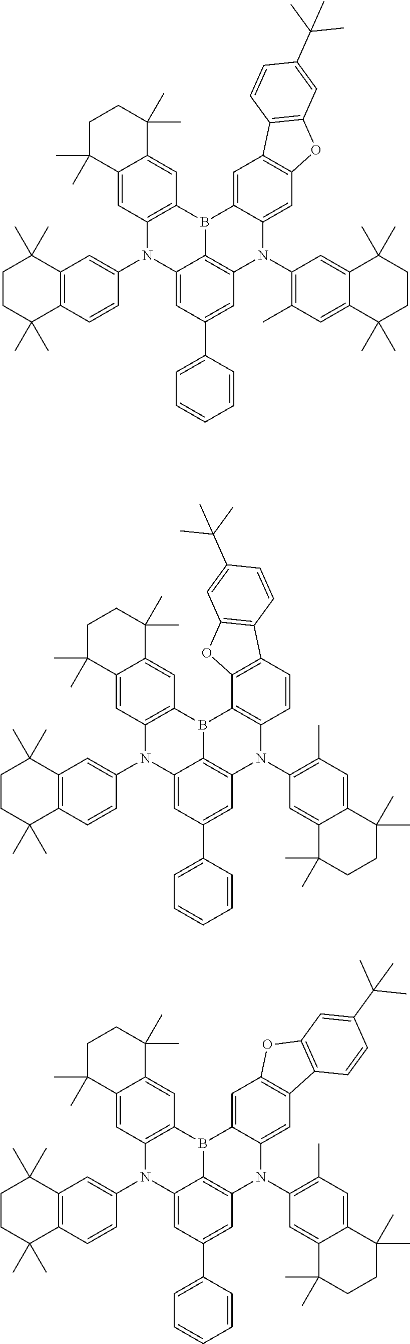 [SMILES: Cc1cc2c(cc1N1c3cc4oc5cc(C(C)(C)C)ccc5c4cc3B3c4cc5c(cc4N(c4ccc6c(c4)C(C)(C)CCC6(C)C)c4cc(-c6ccccc6)cc1c43)C(C)(C)CCC5(C)C)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3c1ccc1c3oc3cc(C(C)(C)C)ccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)oc1cc(C(C)(C)C)ccc14)C(C)(C)CCC2(C)C]

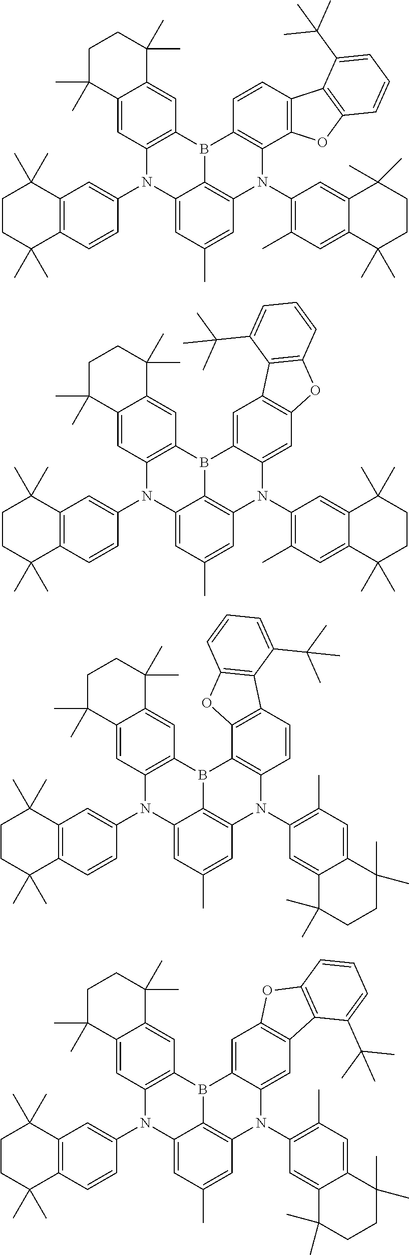

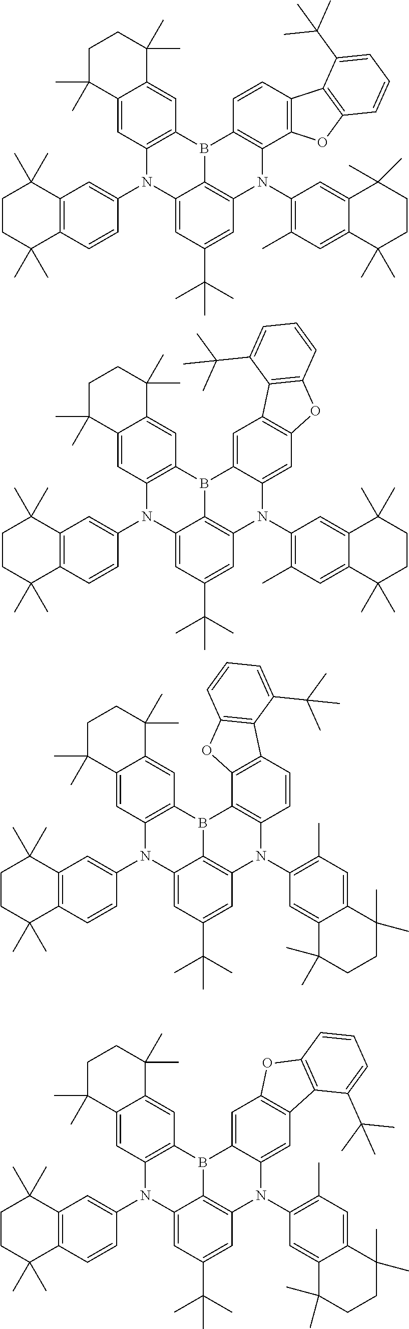

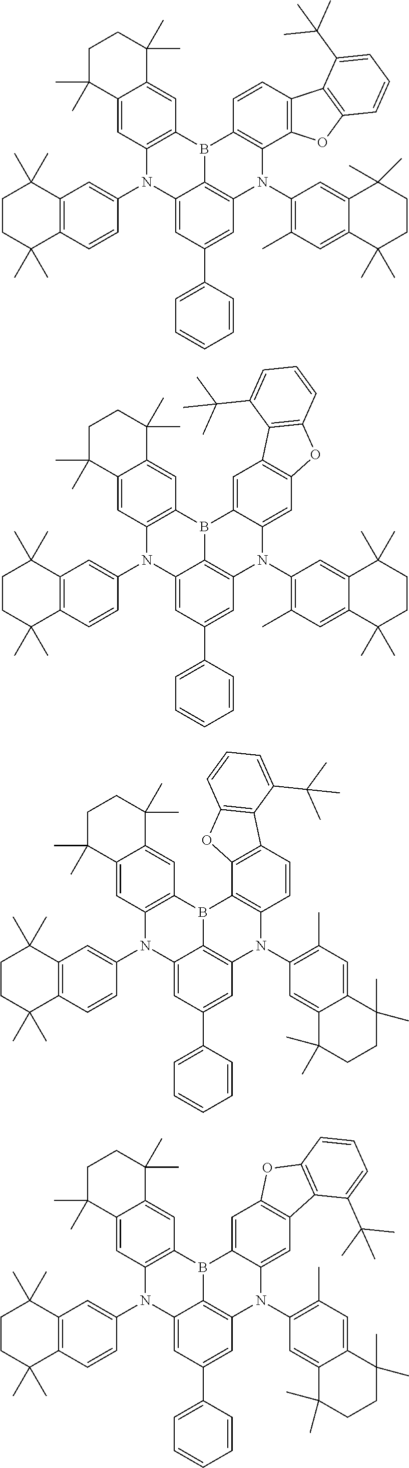

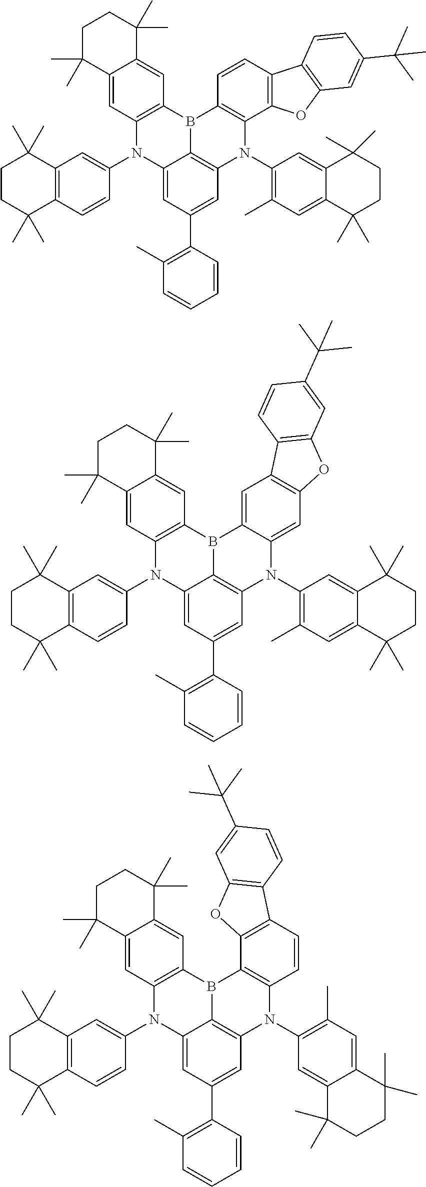

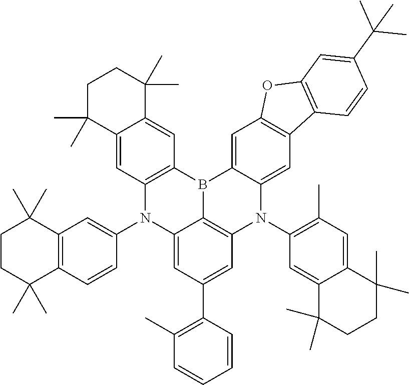 [SMILES: Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1cc(C(C)(C)C)ccc14]

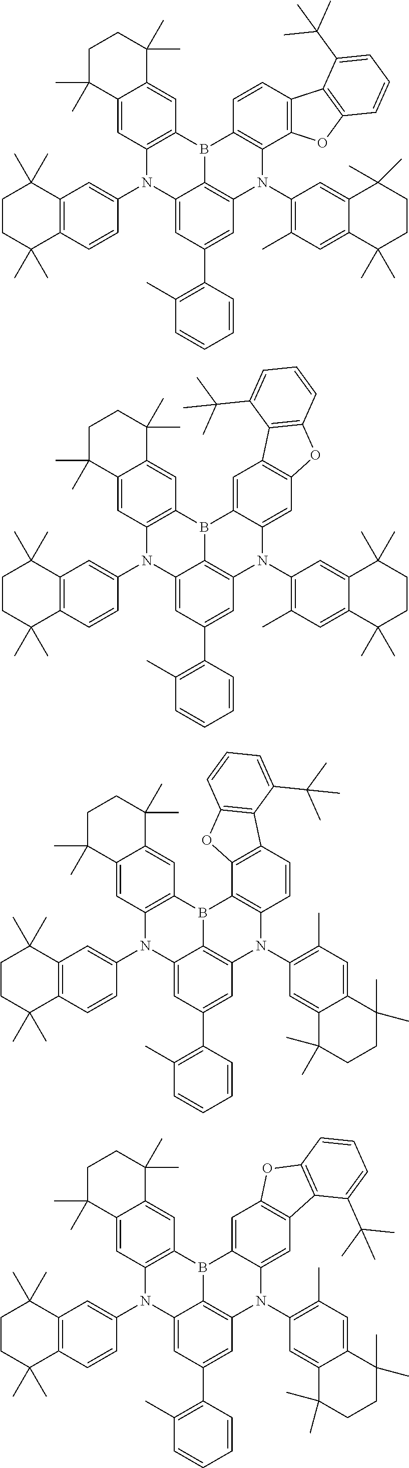

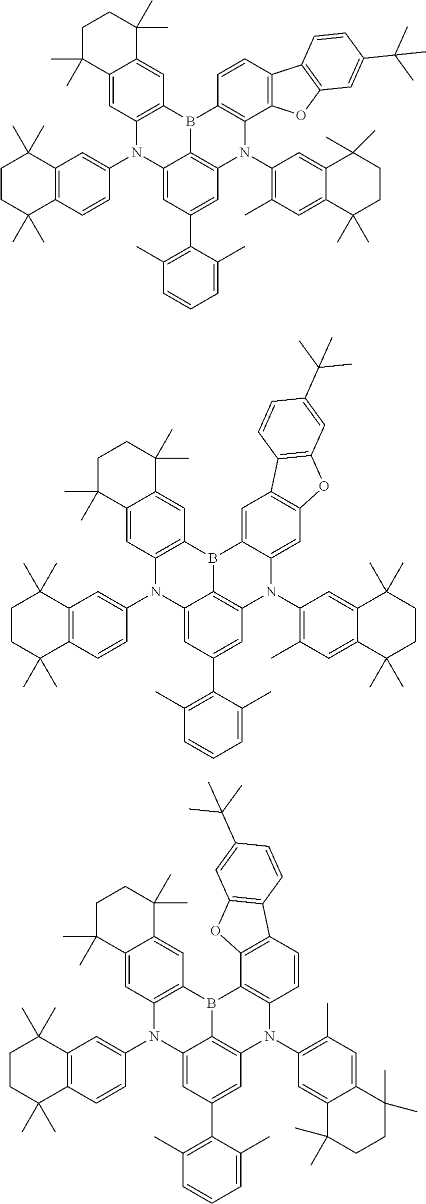

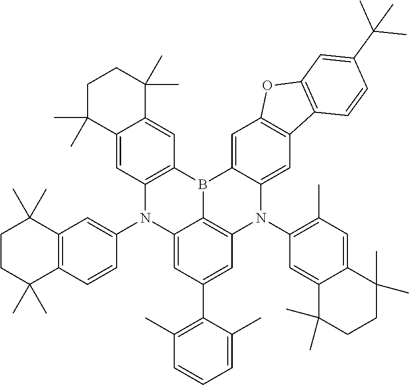 [SMILES: Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)oc1cc(C(C)(C)C)ccc14)C(C)(C)CCC2(C)C]

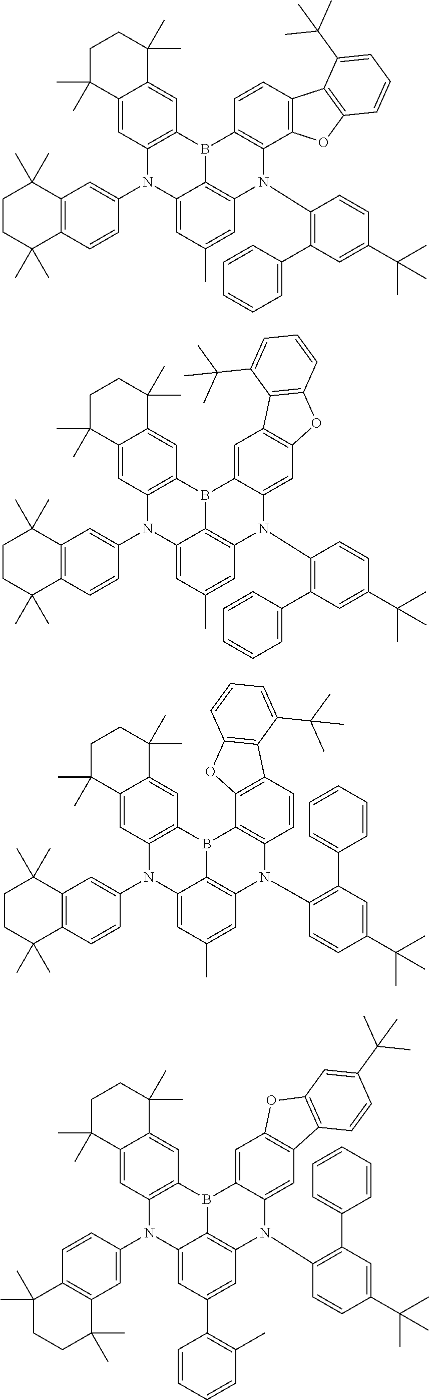

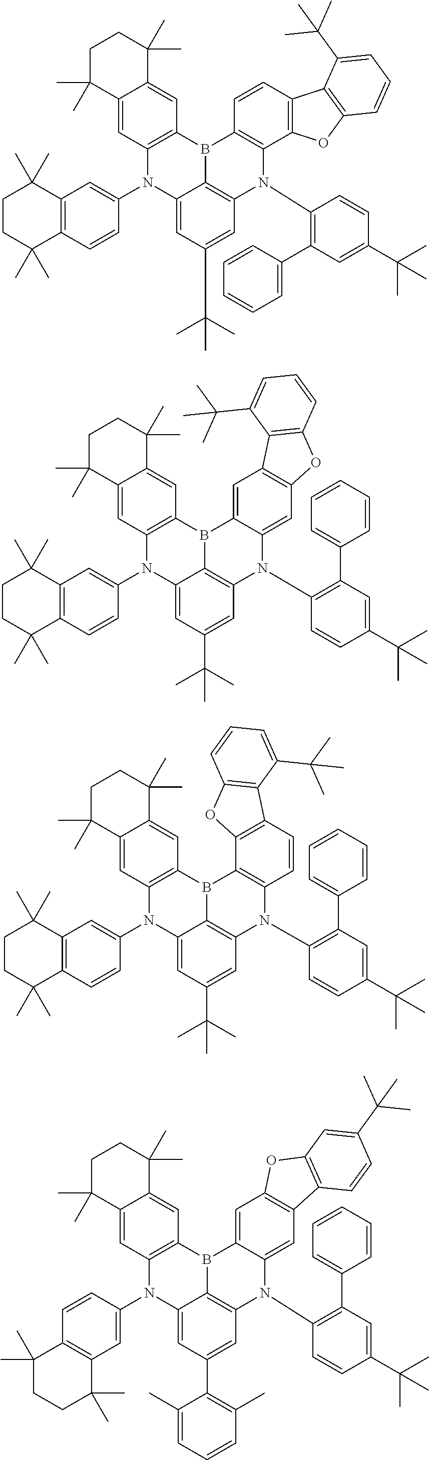

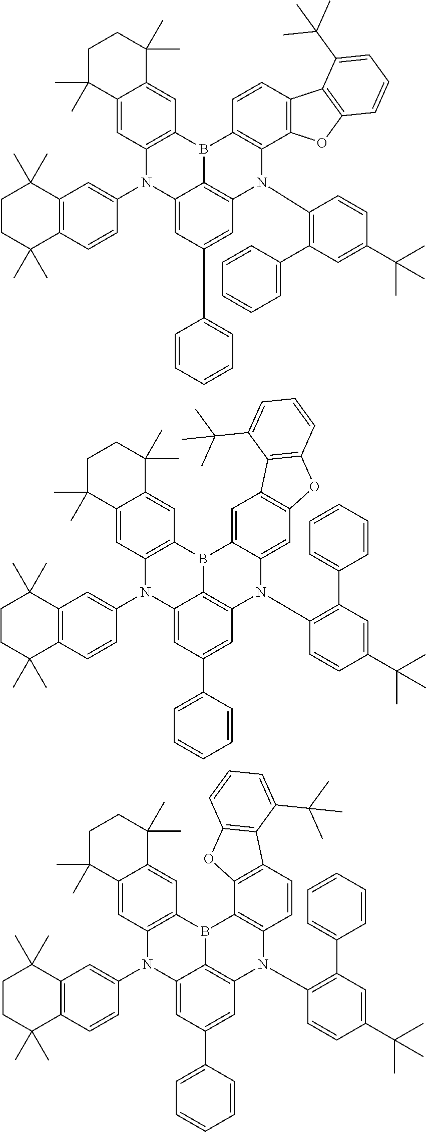

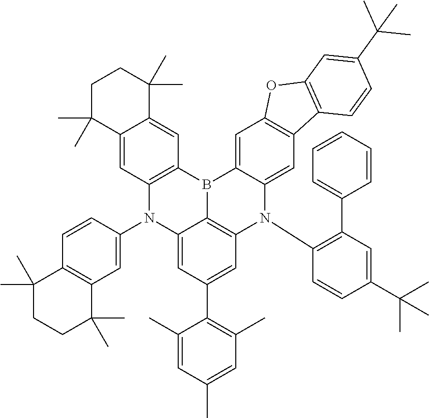 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2cc(C(C)(C)C)ccc25)c(C)c1]

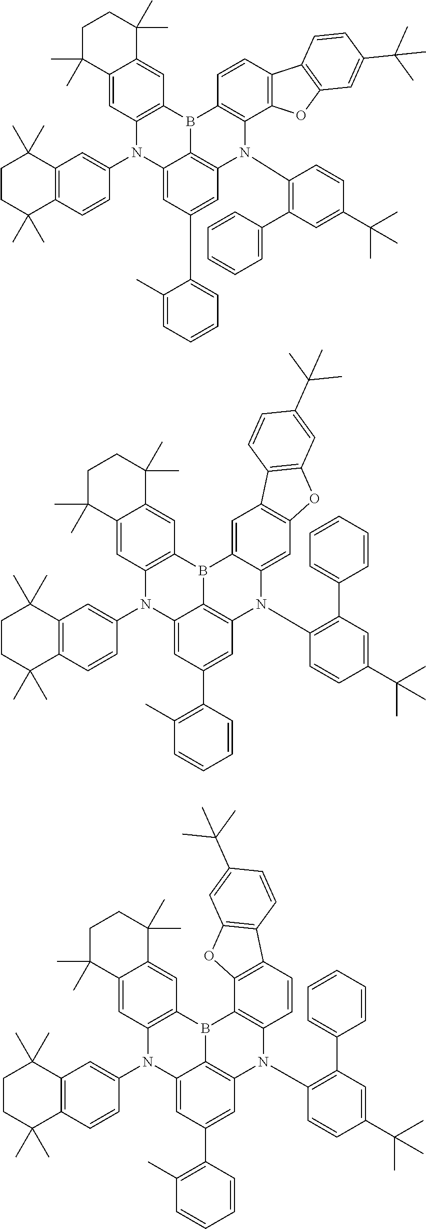

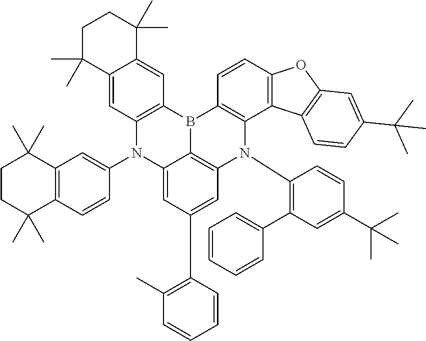 [SMILES: Cc1ccccc1-c1cc2c3c(c1)N(c1ccc(C(C)(C)C)cc1-c1ccccc1)c1c(ccc4oc5cc(C(C)(C)C)ccc5c14)B3c1cc3c(cc1N2c1ccc2c(c1)C(C)(C)CCC2(C)C)C(C)(C)CCC3(C)C]

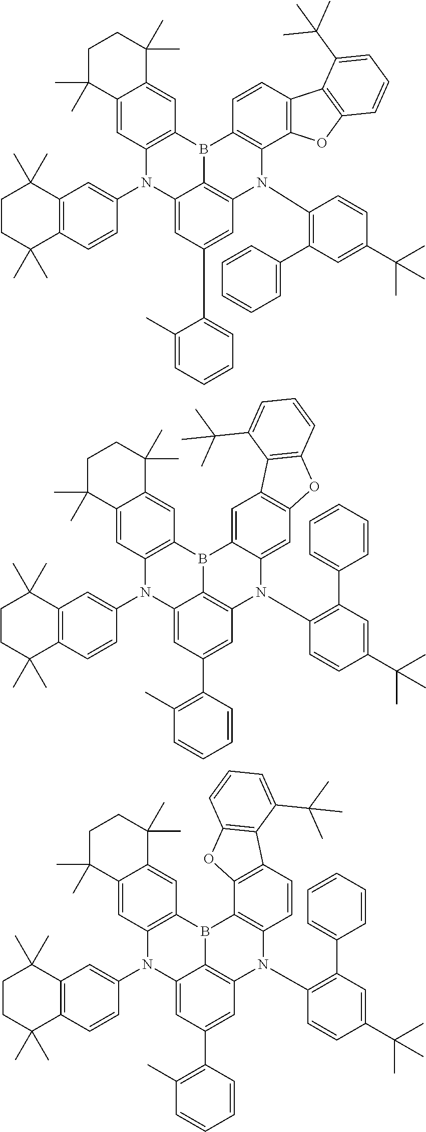

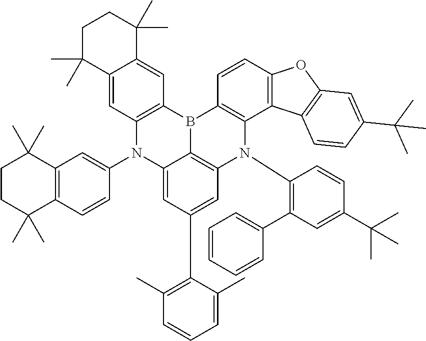 [SMILES: Cc1cccc(C)c1-c1cc2c3c(c1)N(c1ccc(C(C)(C)C)cc1-c1ccccc1)c1c(ccc4oc5cc(C(C)(C)C)ccc5c14)B3c1cc3c(cc1N2c1ccc2c(c1)C(C)(C)CCC2(C)C)C(C)(C)CCC3(C)C]

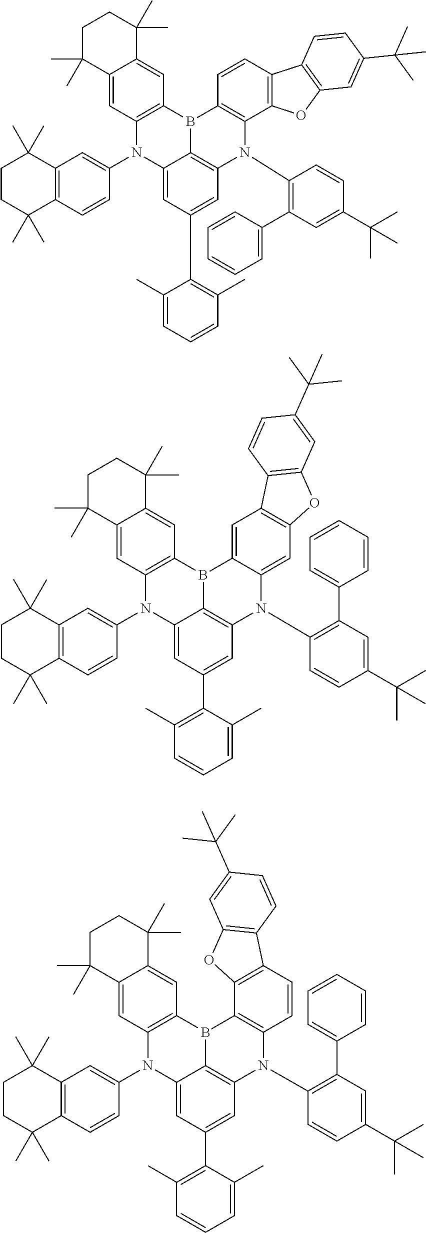

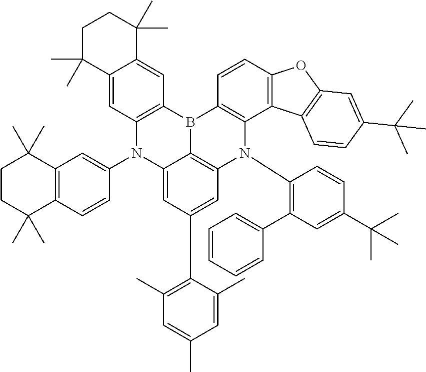 [SMILES: Cc1cc(C)c(-c2cc3c4c(c2)N(c2ccc(C(C)(C)C)cc2-c2ccccc2)c2c(ccc5oc6cc(C(C)(C)C)ccc6c25)B4c2cc4c(cc2N3c2ccc3c(c2)C(C)(C)CCC3(C)C)C(C)(C)CCC4(C)C)c(C)c1]

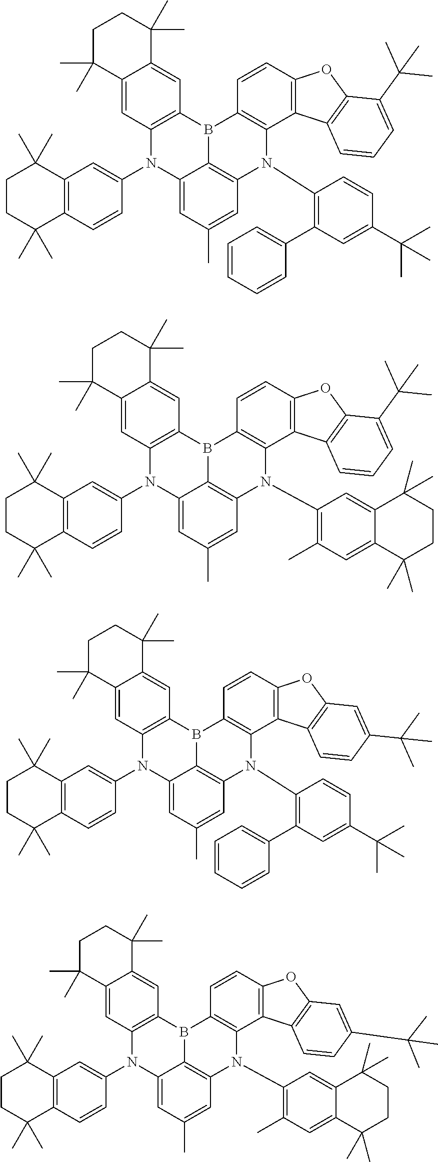

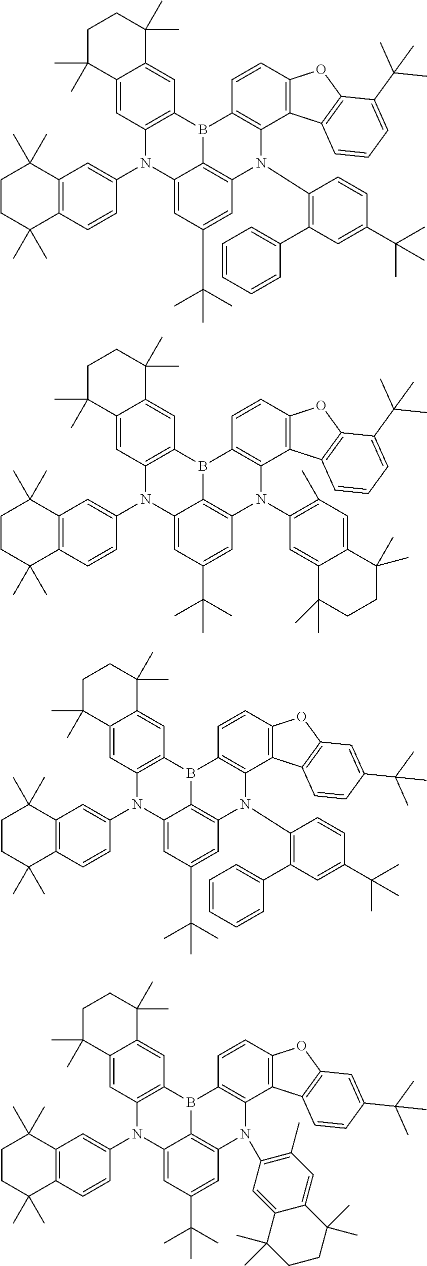

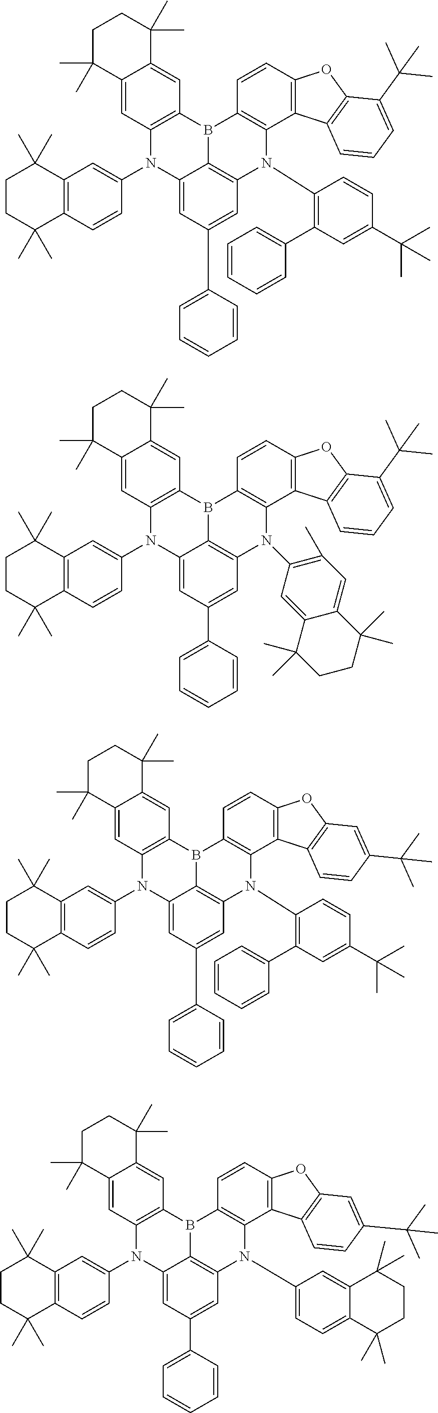

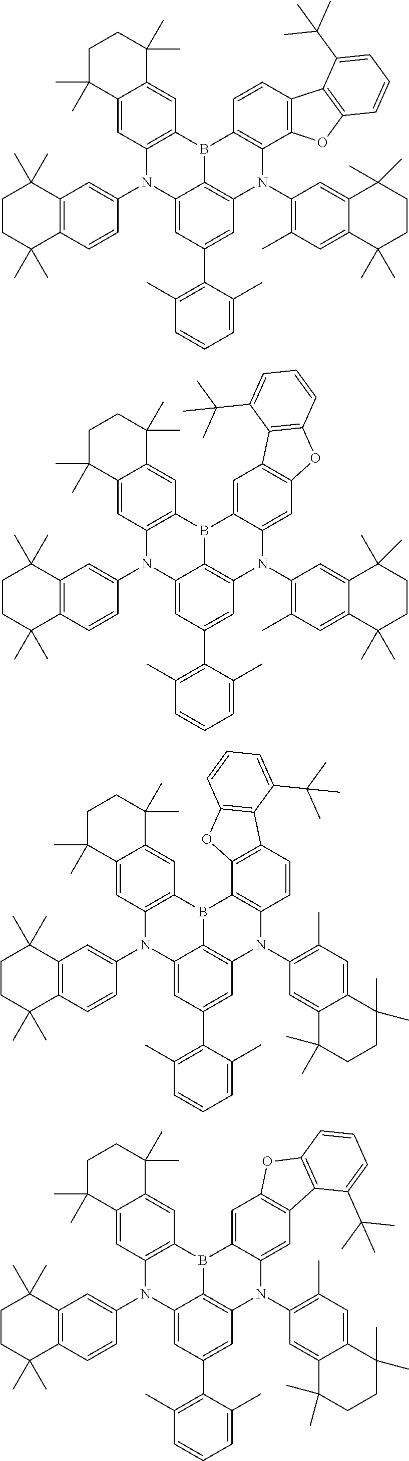

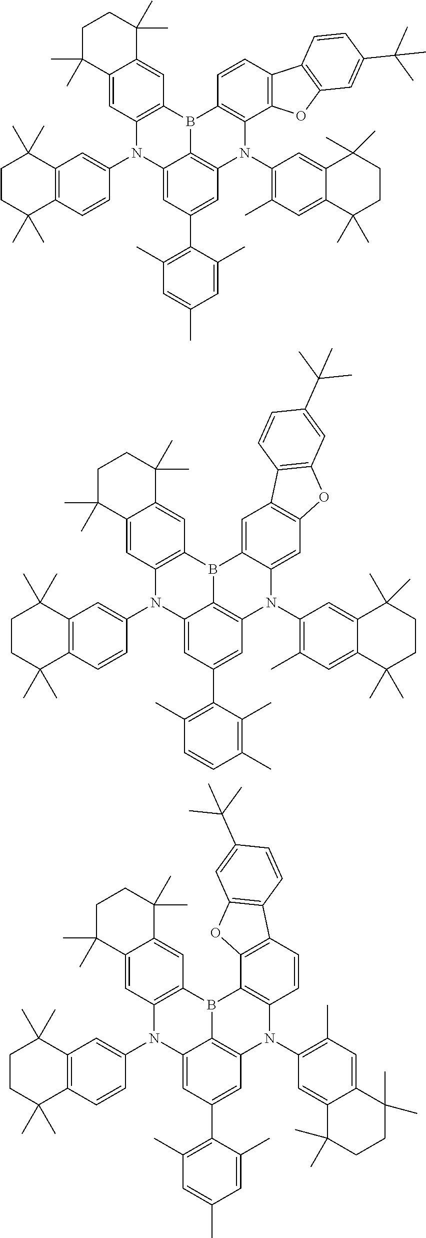

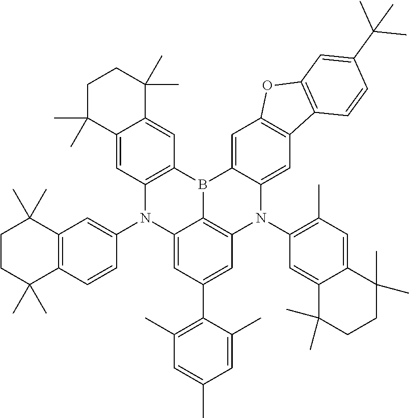 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2cc(C(C)(C)C)ccc25)c(C)c1]

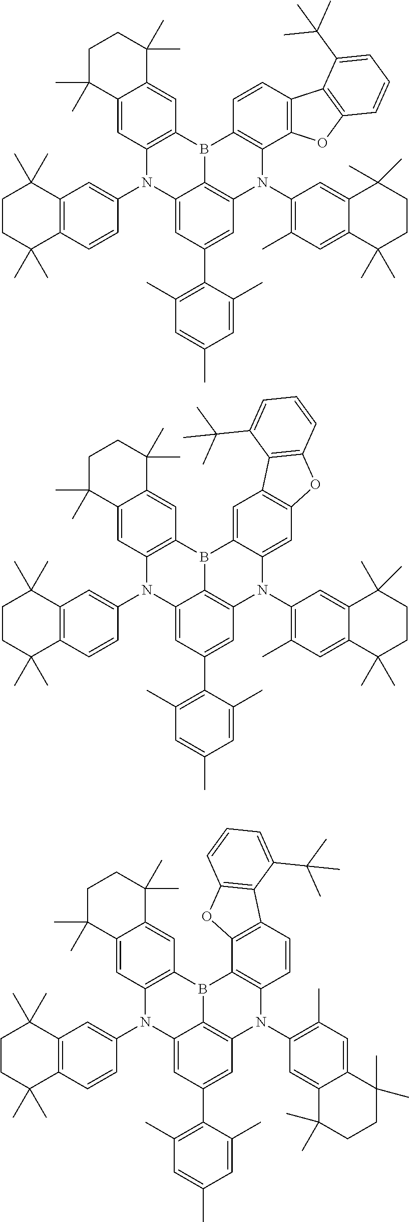

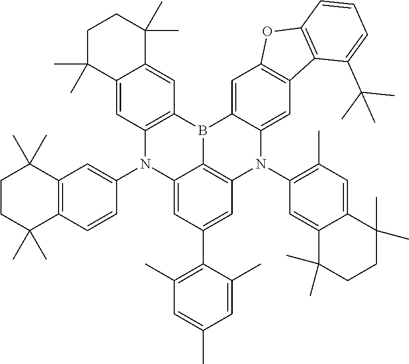 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2cccc(C(C)(C)C)c25)c(C)c1]

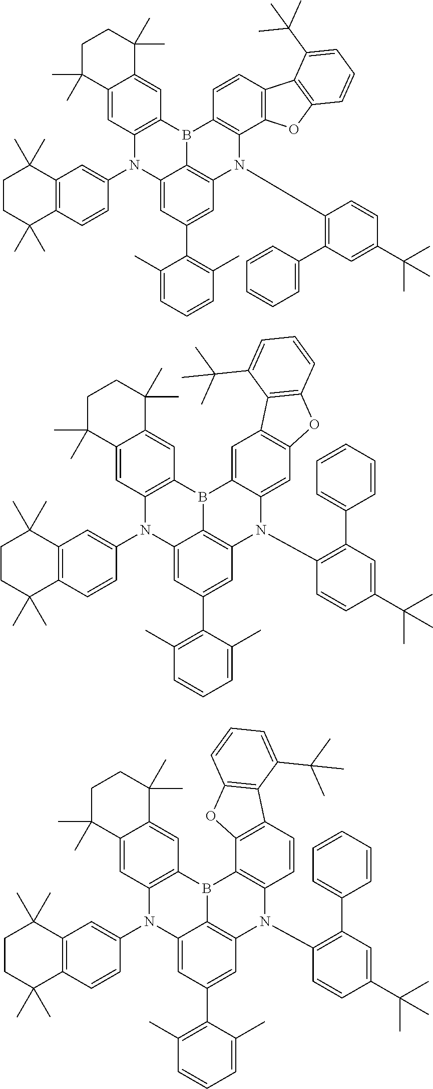

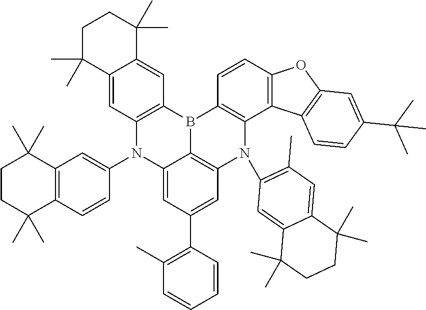 [SMILES: Cc1ccccc1-c1cc2c3c(c1)N(c1cc4c(cc1C)C(C)(C)CCC4(C)C)c1c(ccc4oc5cc(C(C)(C)C)ccc5c14)B3c1cc3c(cc1N2c1ccc2c(c1)C(C)(C)CCC2(C)C)C(C)(C)CCC3(C)C]

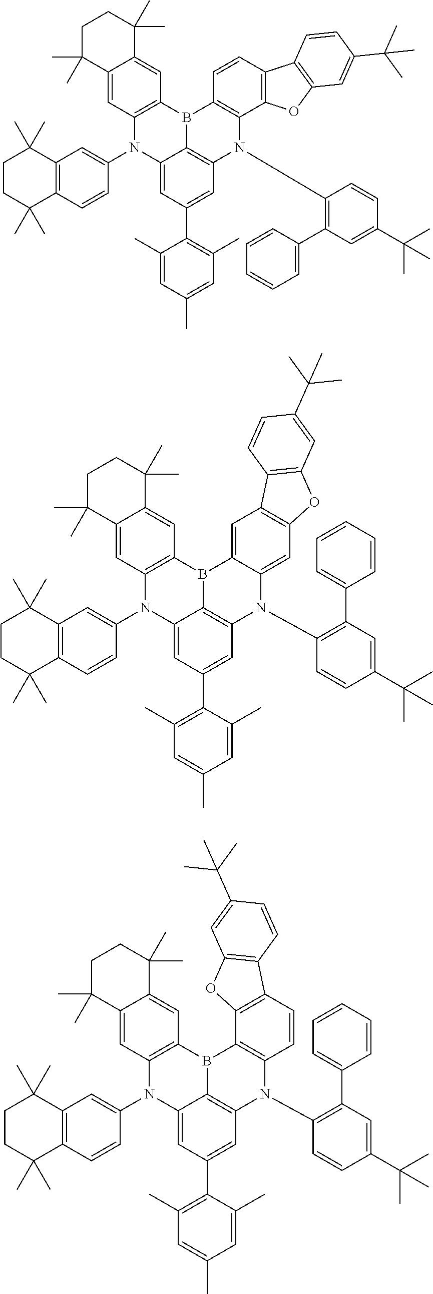

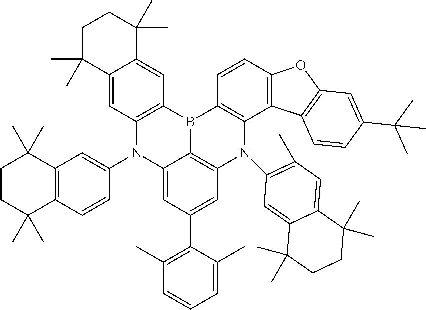 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4oc5cc(C(C)(C)C)ccc5c4c31)C(C)(C)CCC2(C)C]

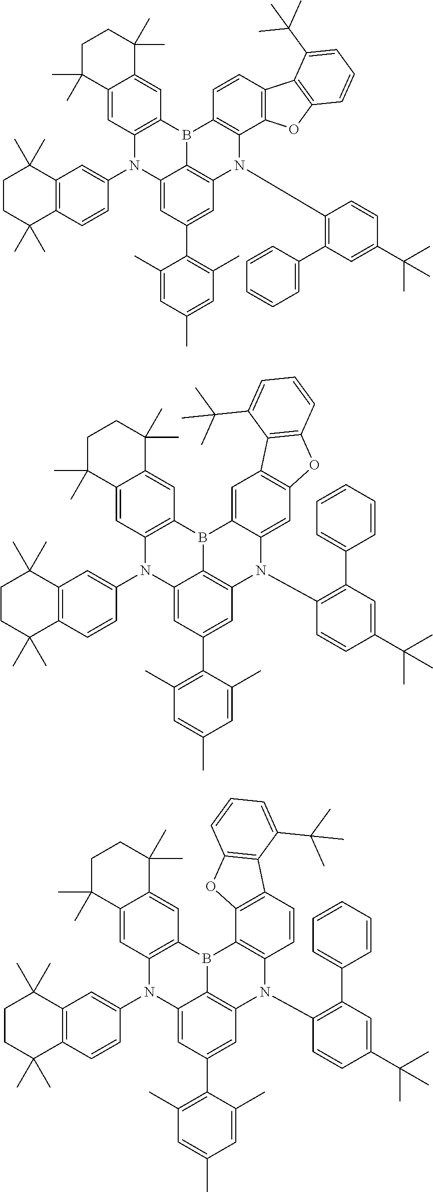

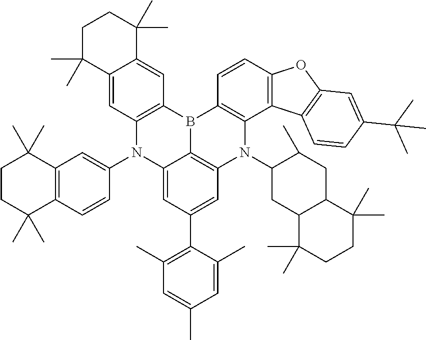 [SMILES: Cc1cc(C)c(-c2cc3c4c(c2)N(C2CC5C(CC2C)C(C)(C)CCC5(C)C)c2c(ccc5oc6cc(C(C)(C)C)ccc6c25)B4c2cc4c(cc2N3c2ccc3c(c2)C(C)(C)CCC3(C)C)C(C)(C)CCC4(C)C)c(C)c1]

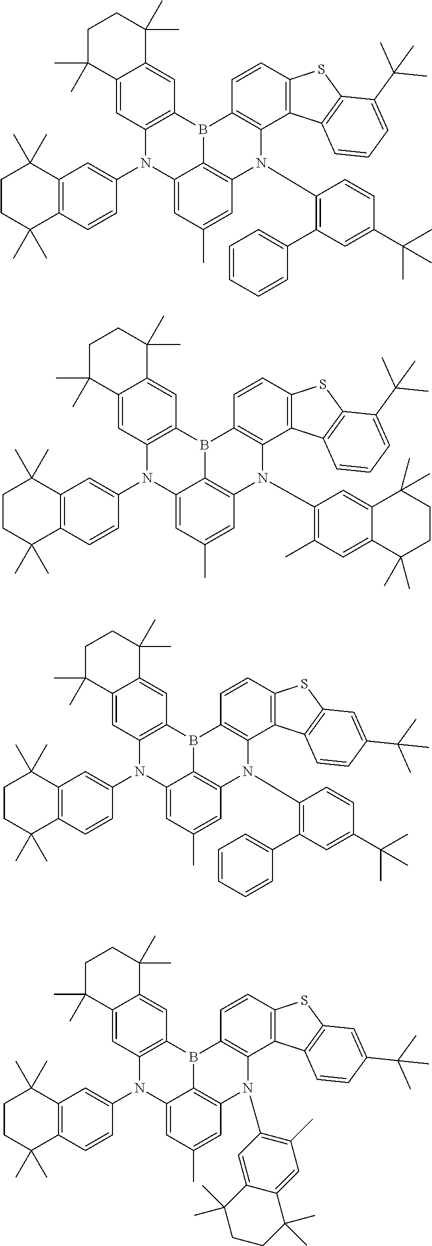

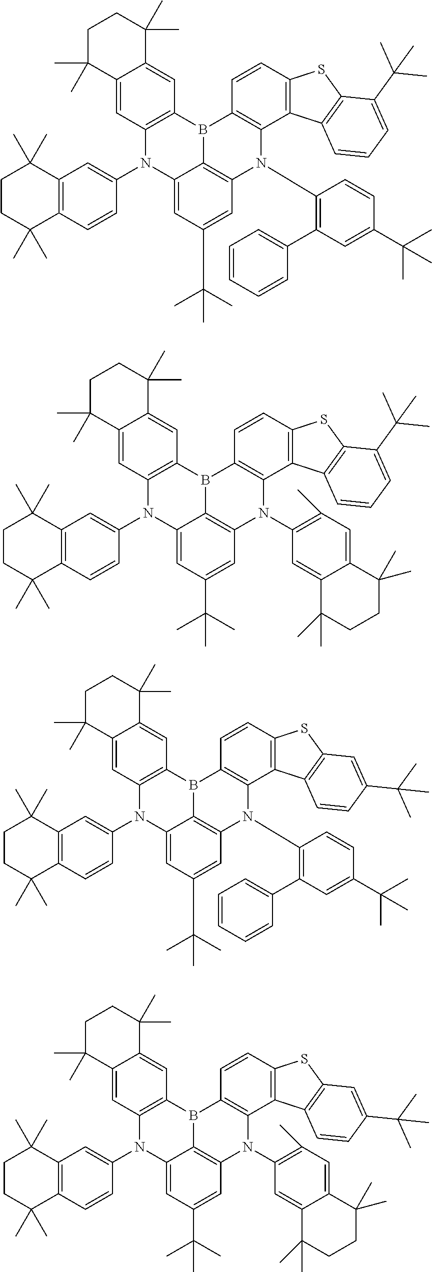

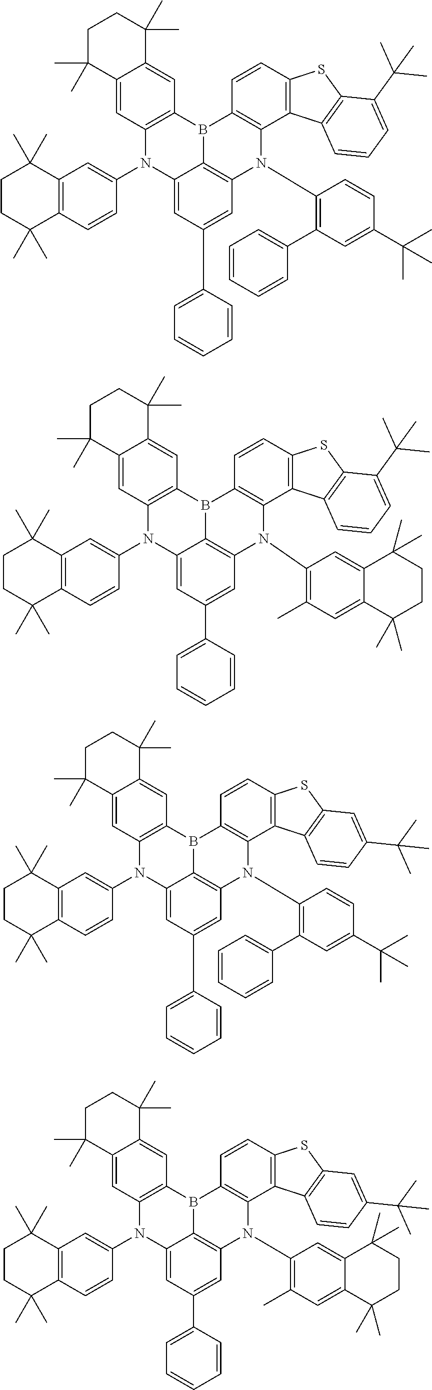

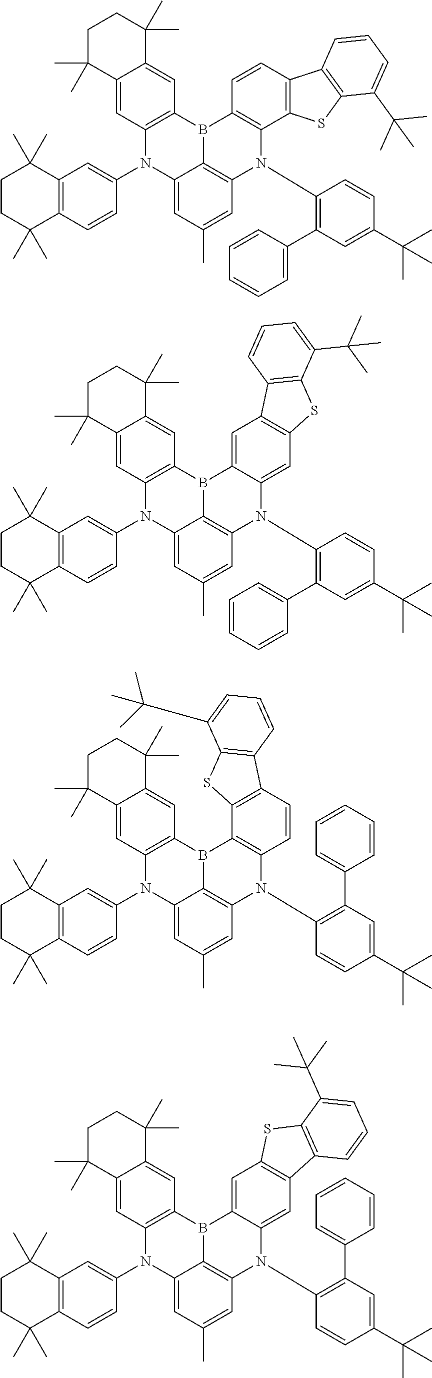

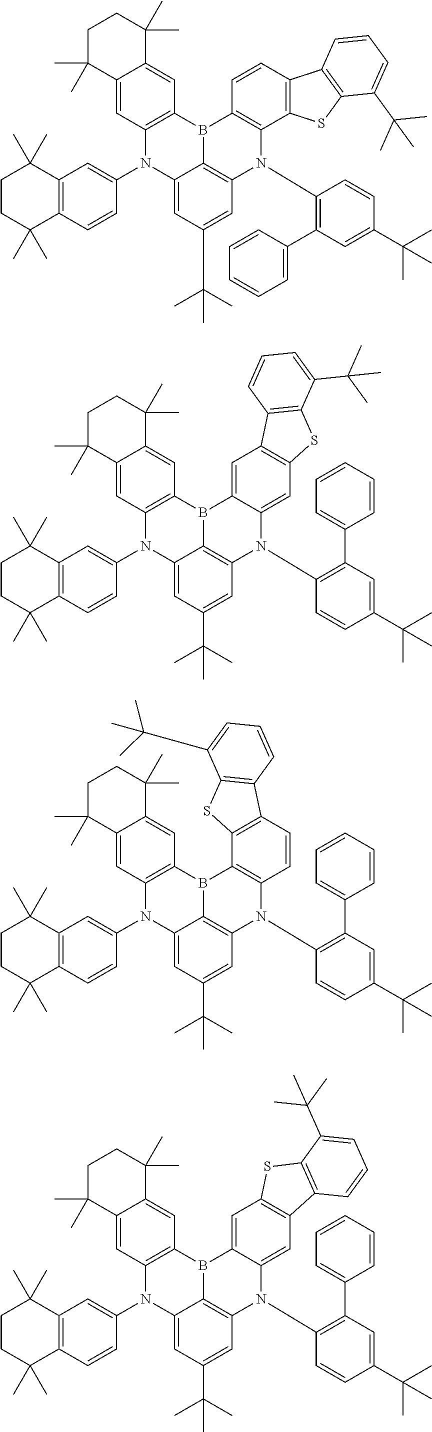

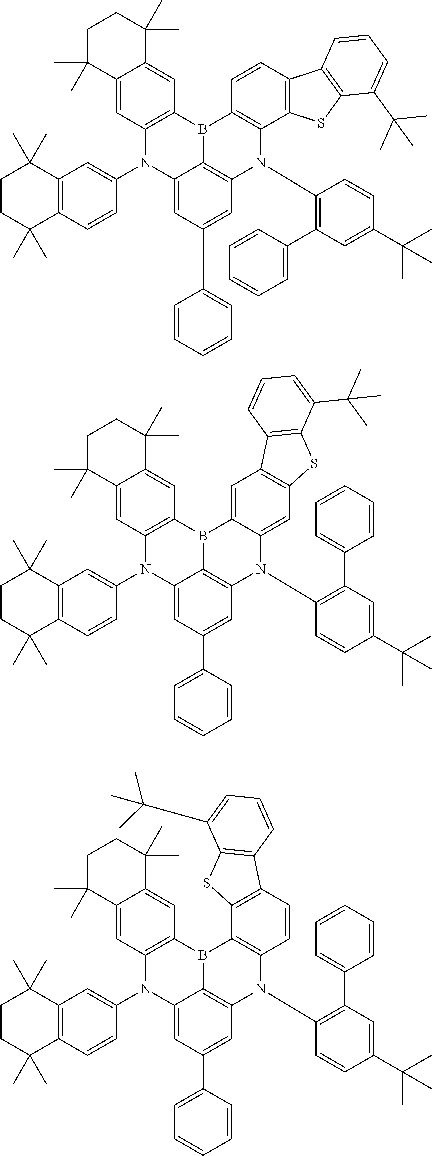 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(sc5c(C(C)(C)C)cccc54)c32)c(-c2ccccc2)c1 ; CC(C)(C)c1ccc(N2c3cc4sc5c(C(C)(C)C)cccc5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3sc3c(C(C)(C)C)cccc32)c(-c2ccccc2)c1]

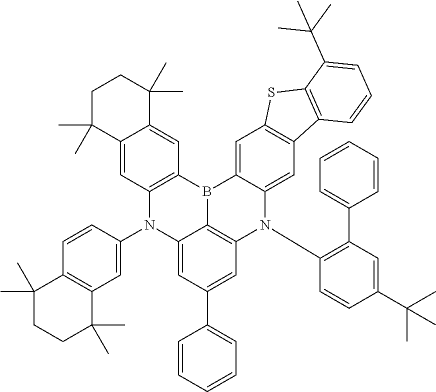 [SMILES: CC(C)(C)c1ccc(N2c3cc4c(cc3B3c5cc6c(cc5N(c5ccc7c(c5)C(C)(C)CCC7(C)C)c5cc(-c7ccccc7)cc2c53)C(C)(C)CCC6(C)C)sc2c(C(C)(C)C)cccc24)c(-c2ccccc2)c1]

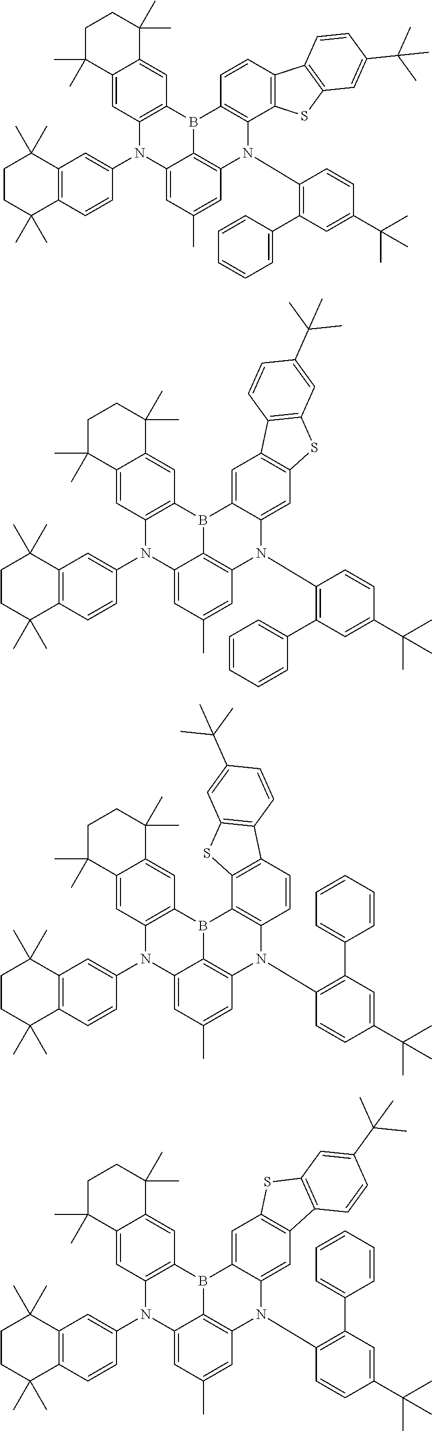

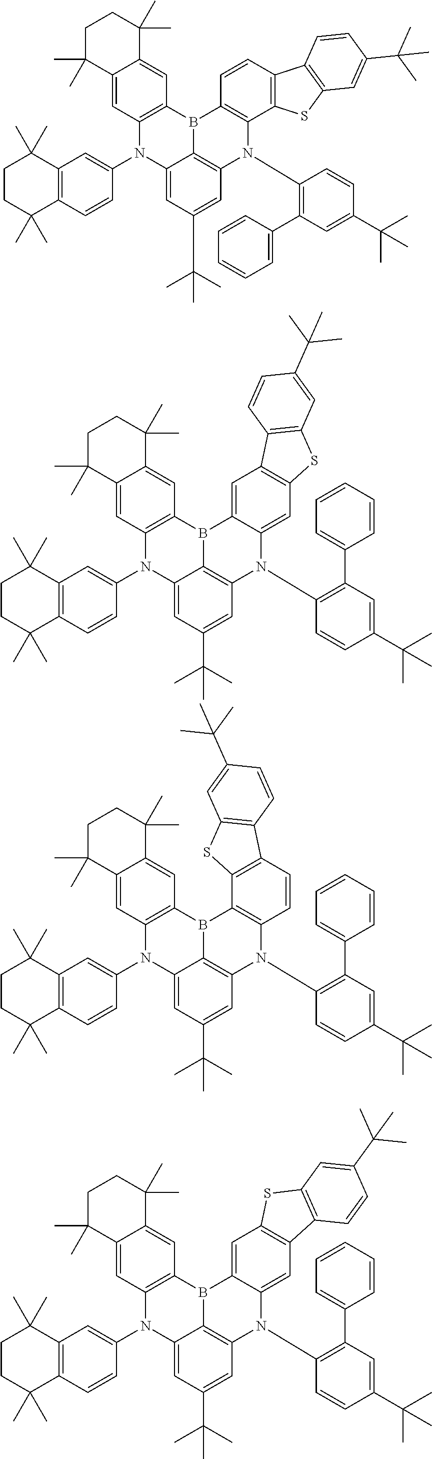

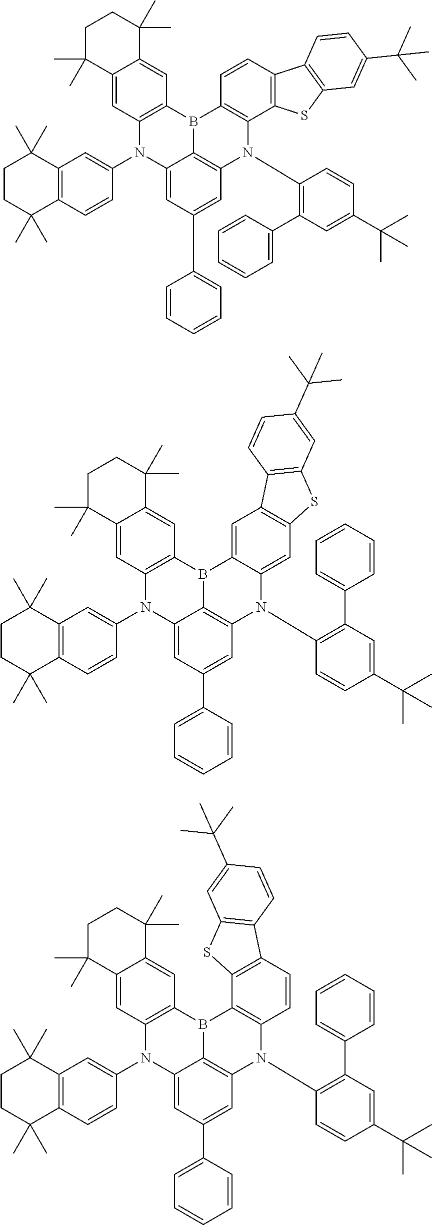

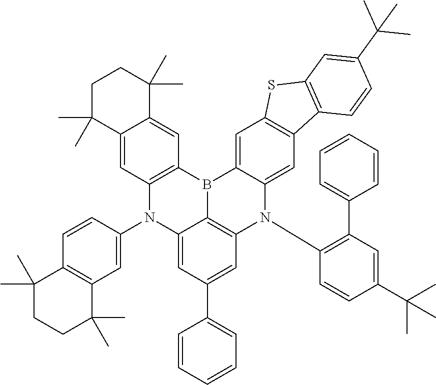 [SMILES: CC(C)(C)c1ccc(N2c3cc4c(cc3B3c5cc6c(cc5N(c5ccc7c(c5)C(C)(C)CCC7(C)C)c5cc(-c7ccccc7)cc2c53)C(C)(C)CCC6(C)C)sc2cc(C(C)(C)C)ccc24)c(-c2ccccc2)c1]

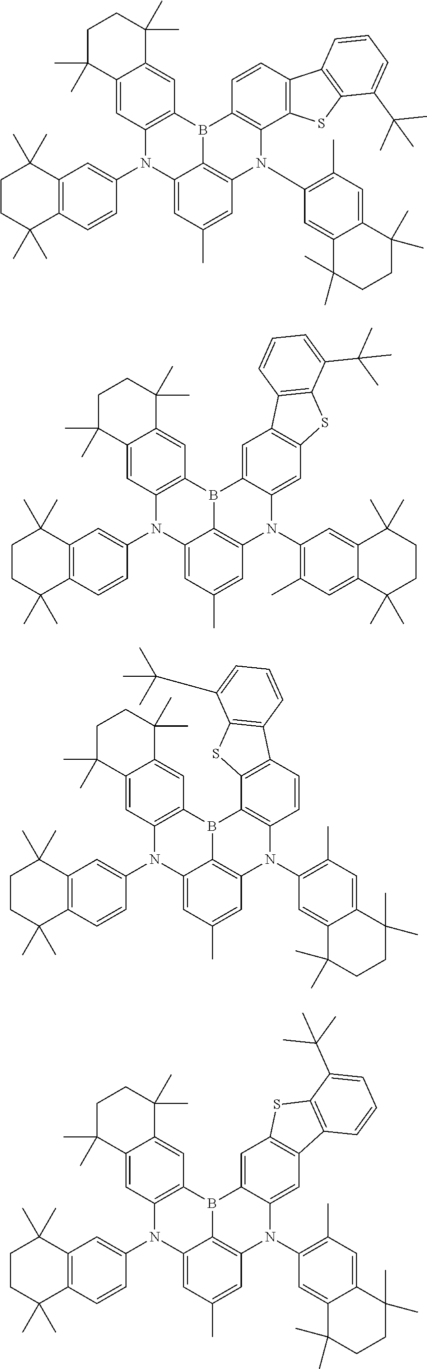

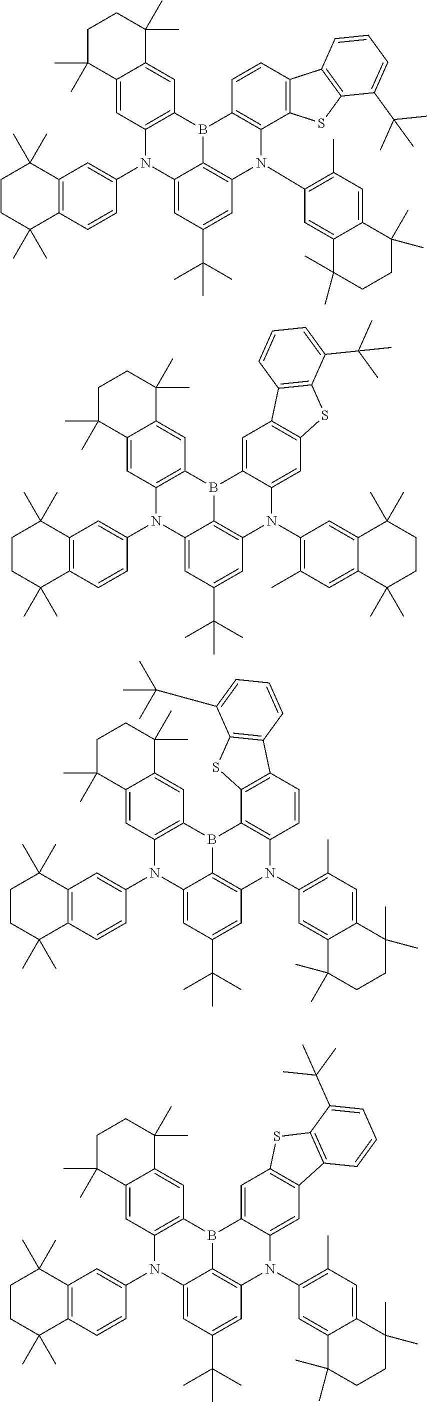

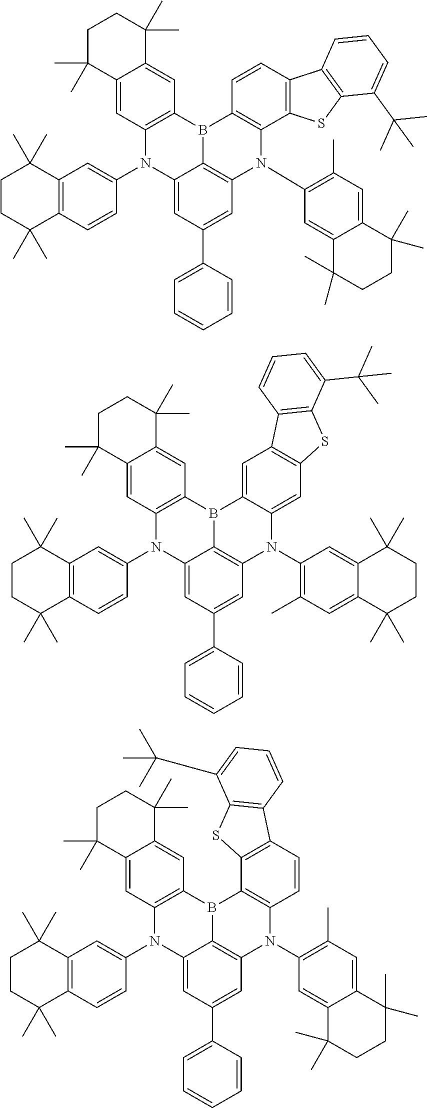

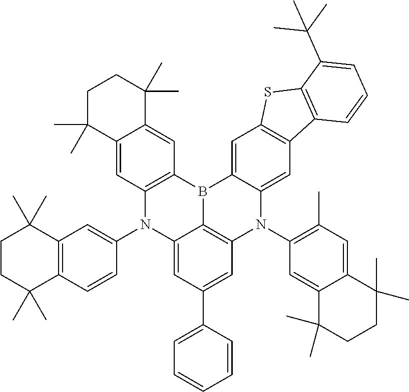 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)sc1c(C(C)(C)C)cccc14)C(C)(C)CCC2(C)C]

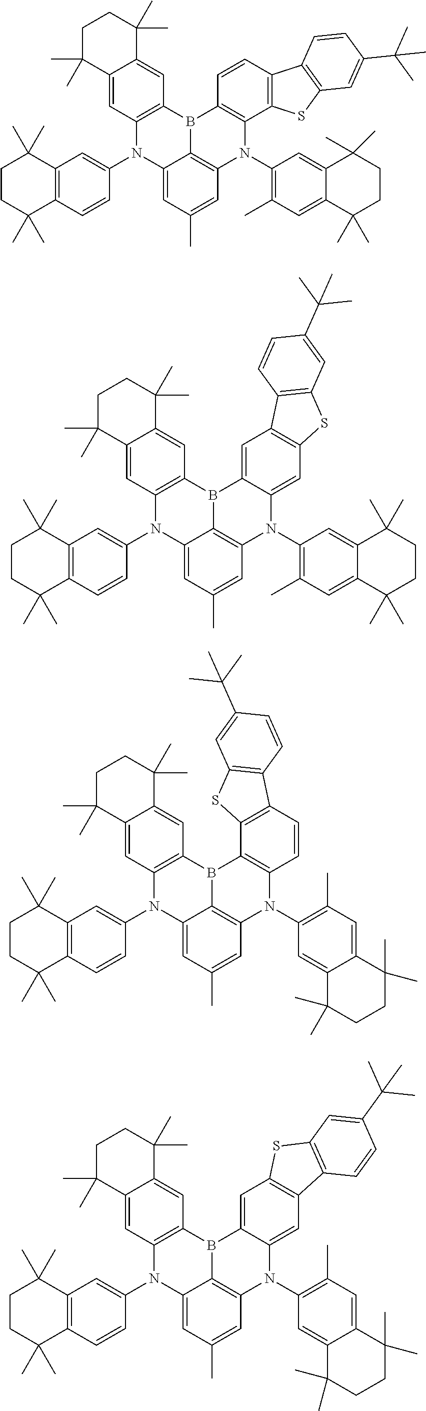

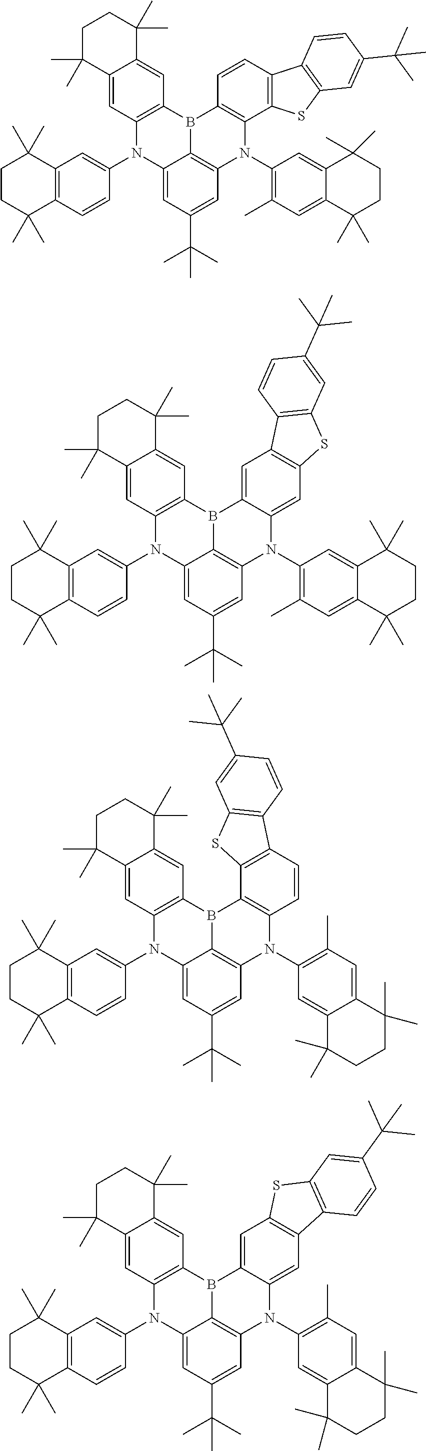

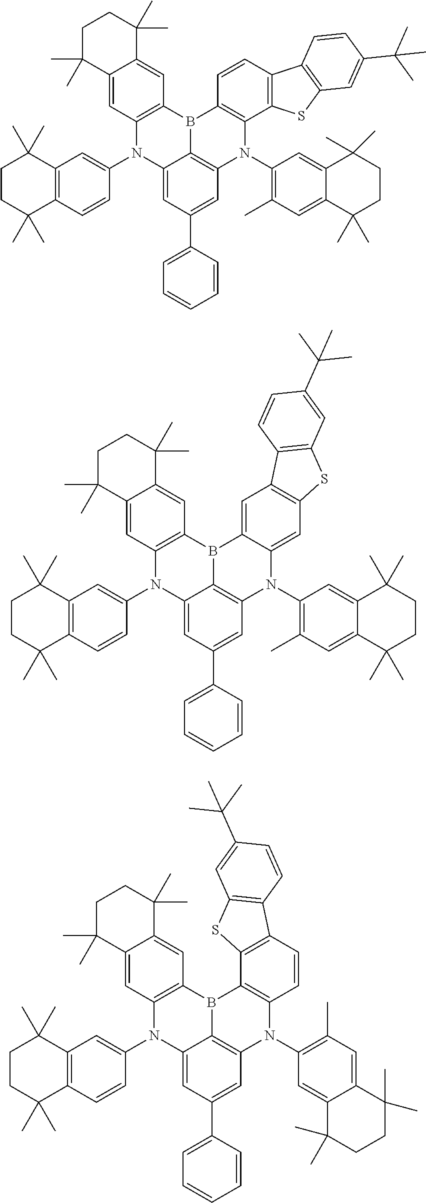

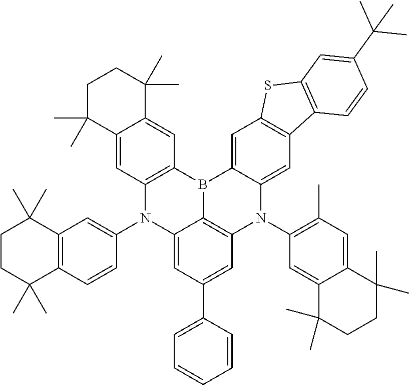 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)sc1cc(C(C)(C)C)ccc14)C(C)(C)CCC2(C)C]

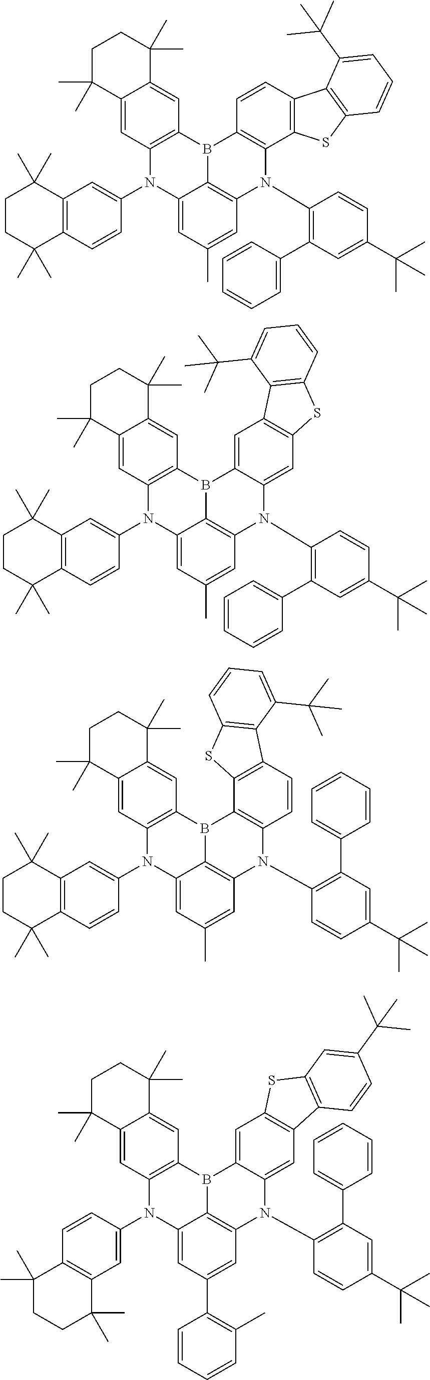

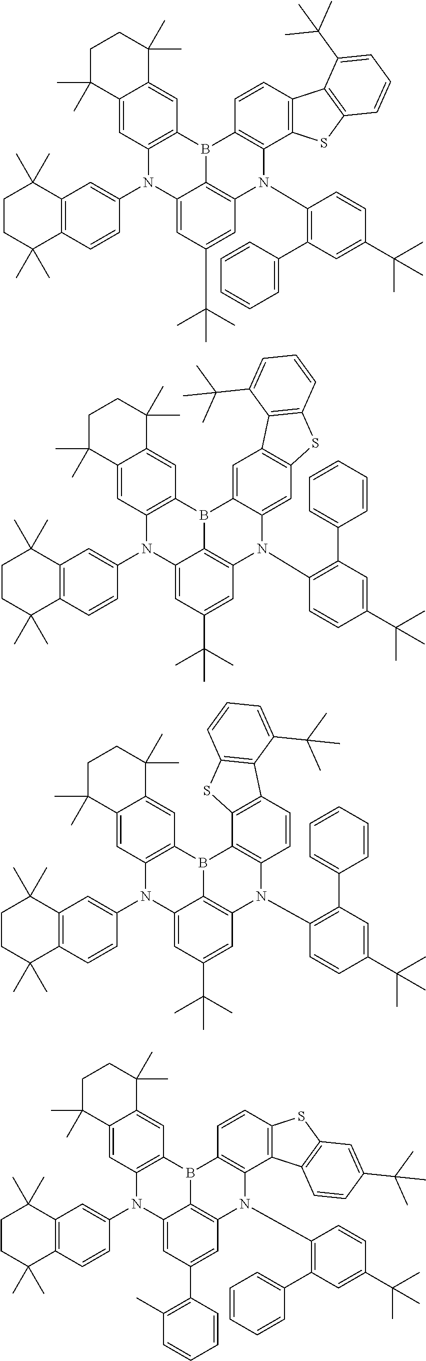

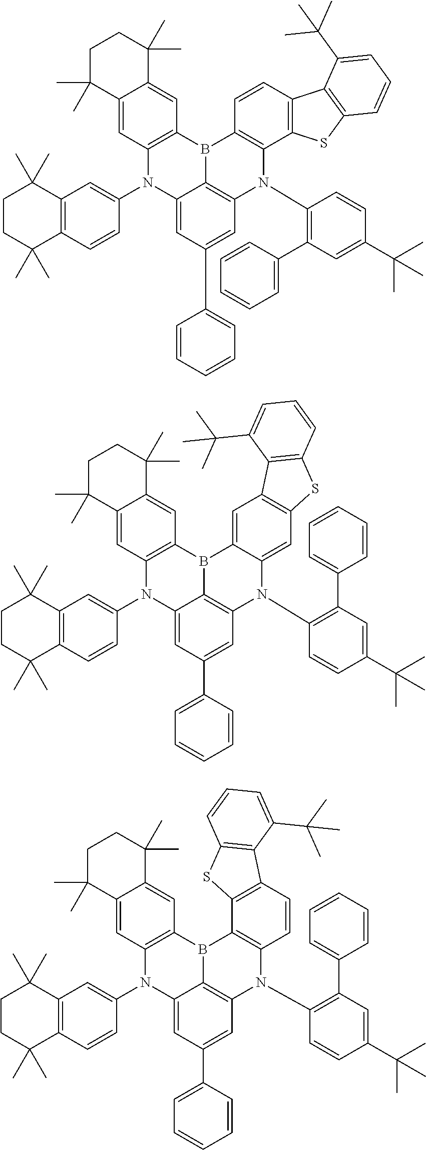

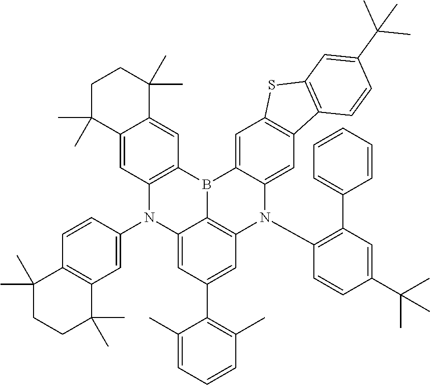 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1cc(C(C)(C)C)ccc14]

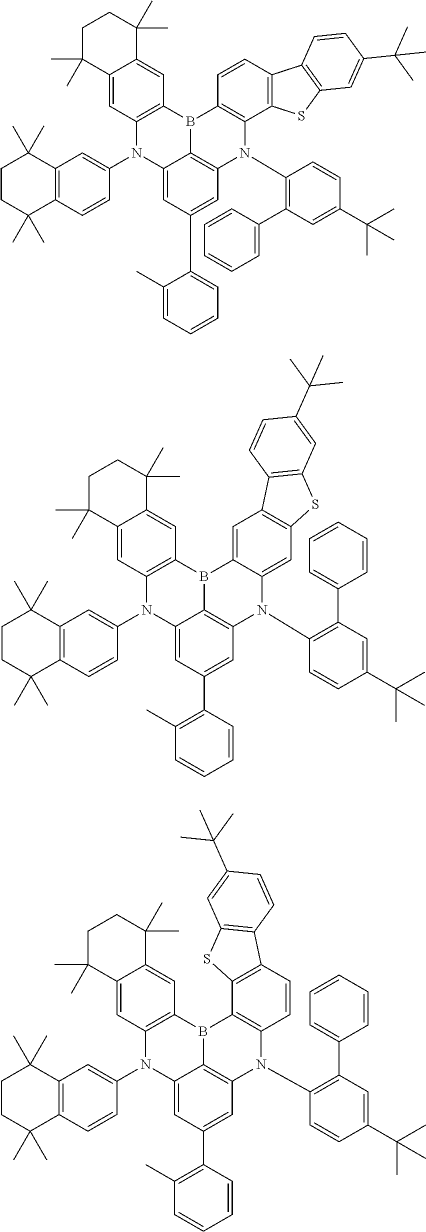

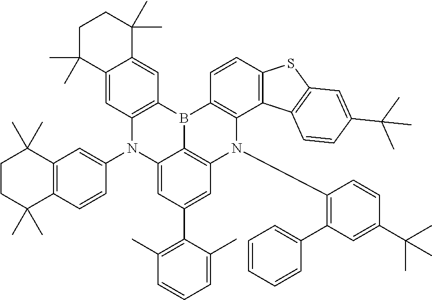 [SMILES: Cc1cccc(C)c1-c1cc2c3c(c1)N(c1ccc(C(C)(C)C)cc1-c1ccccc1)c1c(ccc4sc5cc(C(C)(C)C)ccc5c14)B3c1cc3c(cc1N2c1ccc2c(c1)C(C)(C)CCC2(C)C)C(C)(C)CCC3(C)C]

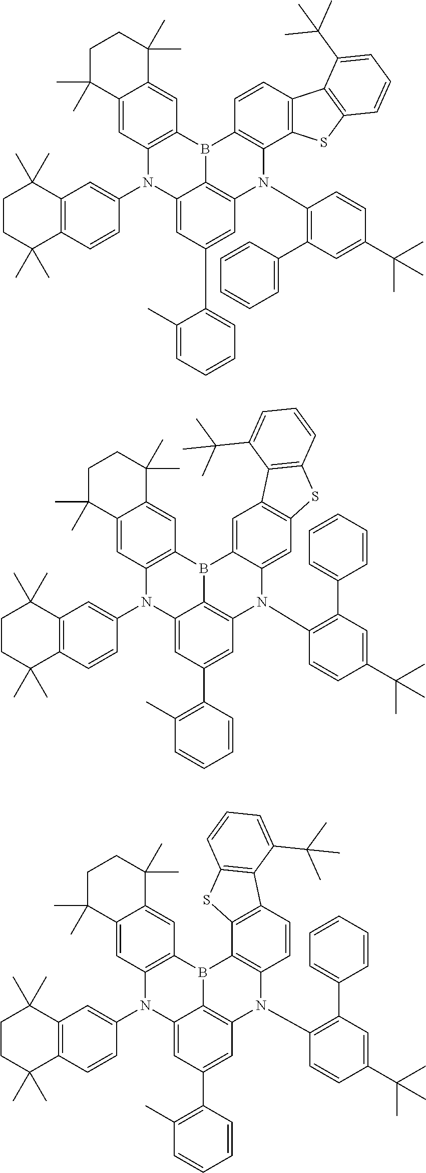

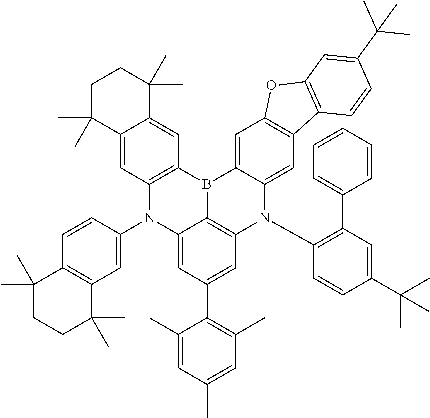 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2cc(C(C)(C)C)ccc25)c(C)c1]

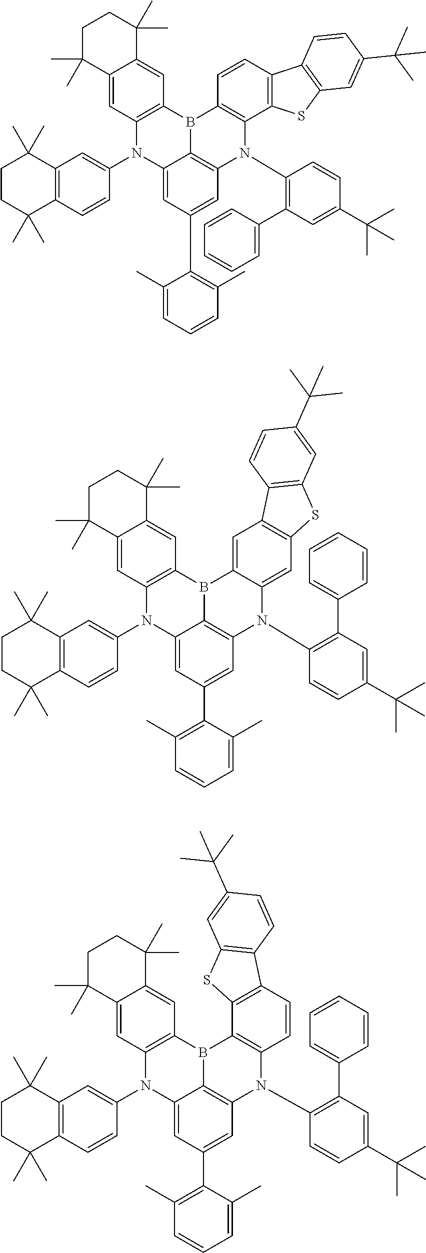

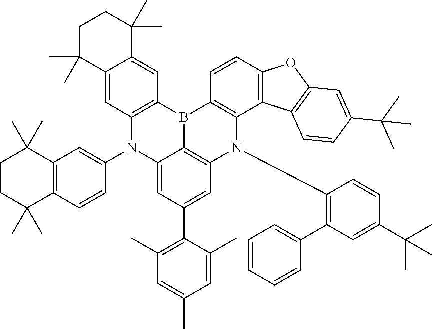 [SMILES: Cc1cc(C)c(-c2cc3c4c(c2)N(c2ccc(C(C)(C)C)cc2-c2ccccc2)c2c(ccc5oc6cc(C(C)(C)C)ccc6c25)B4c2cc4c(cc2N3c2ccc3c(c2)C(C)(C)CCC3(C)C)C(C)(C)CCC4(C)C)c(C)c1]

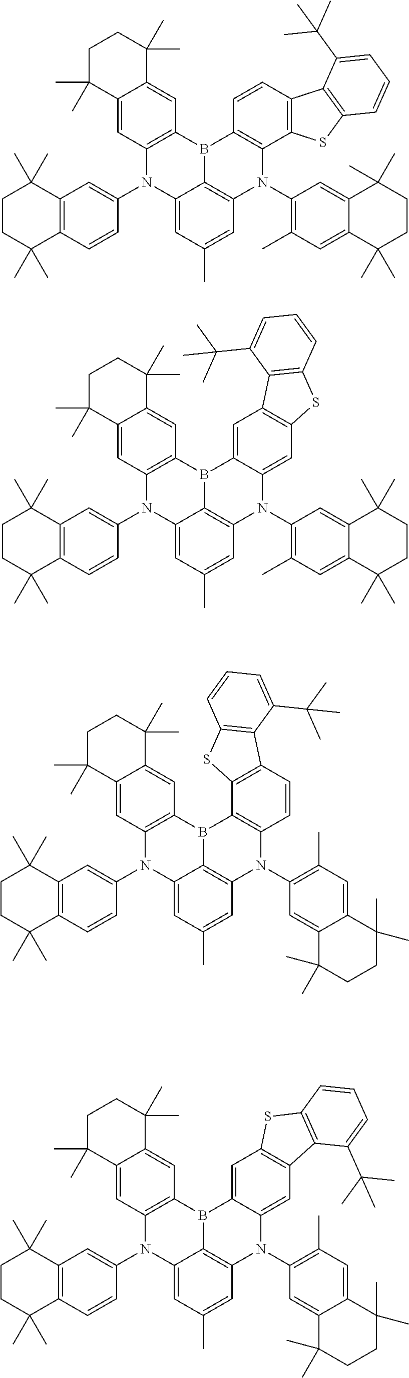

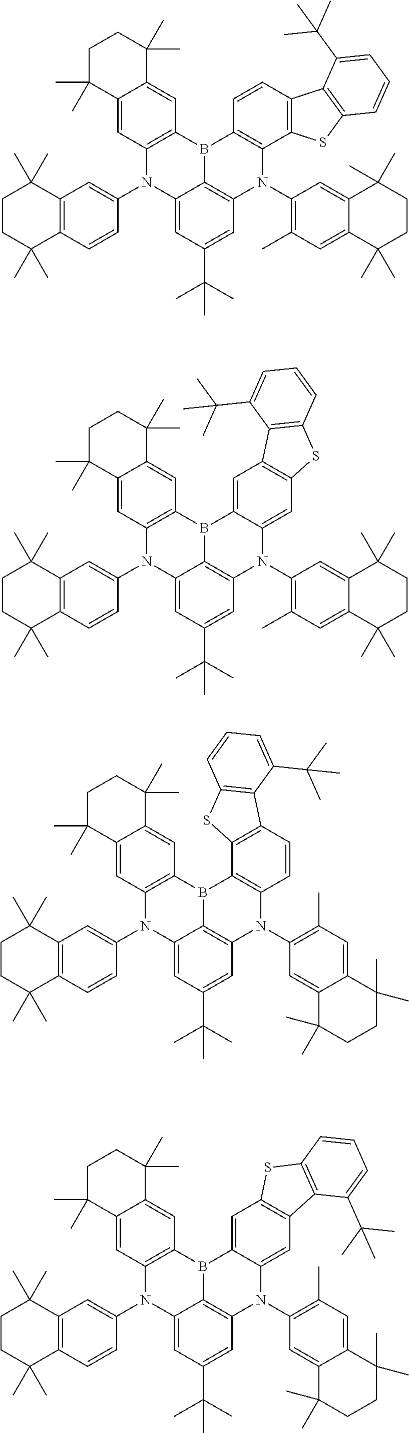

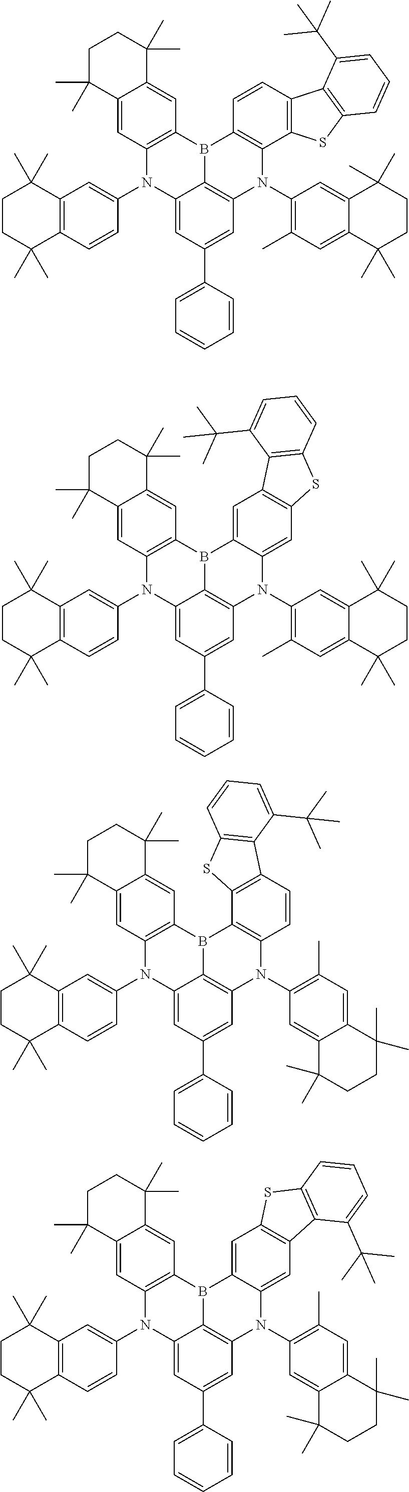

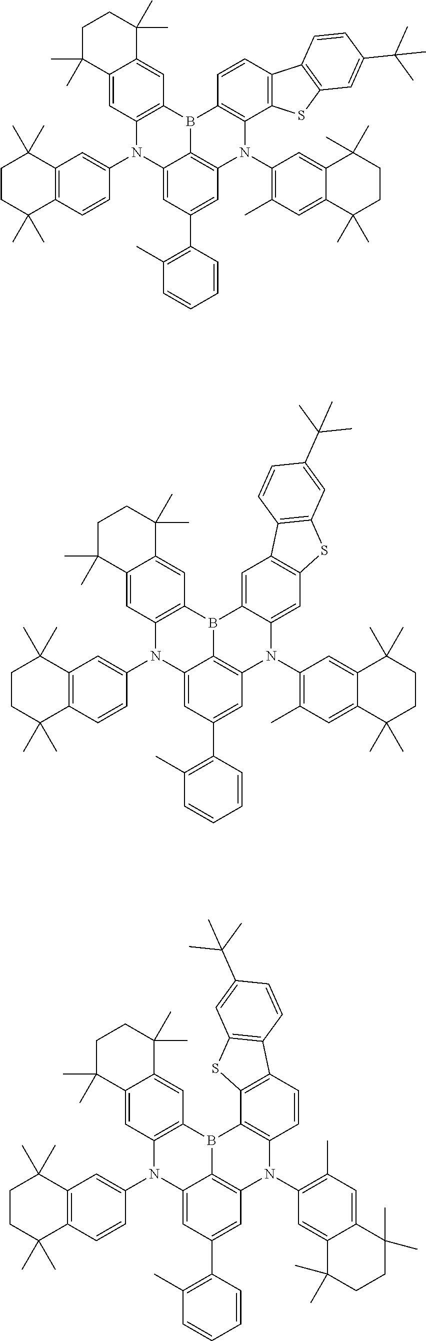 [SMILES: Cc1ccccc1-c1cc2c3c(c1)N(c1cc4c(cc1C)C(C)(C)CCC4(C)C)c1c(ccc4c1sc1cc(C(C)(C)C)ccc14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4sc5cc(C(C)(C)C)ccc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1ccc4c(sc5cc(C(C)(C)C)ccc54)c1B3c1cc3c(cc1N2c1ccc2c(c1)C(C)(C)CCC2(C)C)C(C)(C)CCC3(C)C]

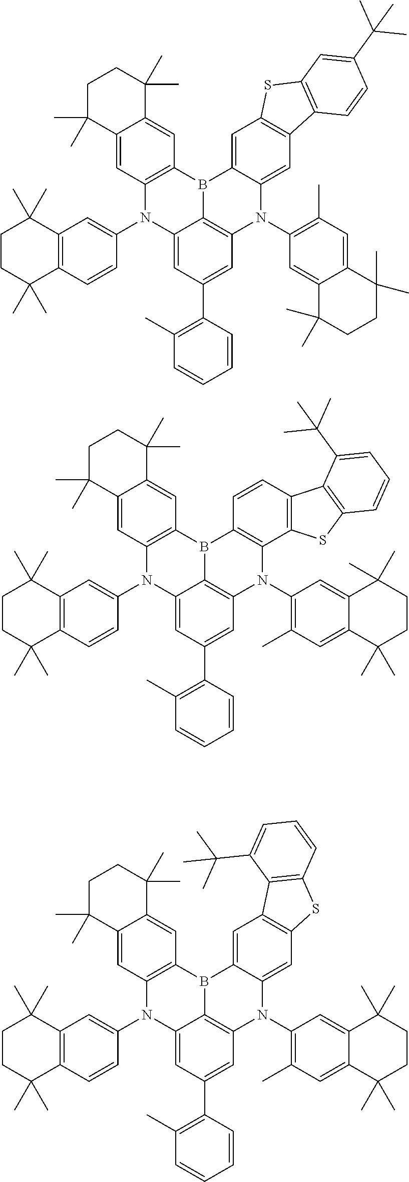 [SMILES: Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1cc(C(C)(C)C)ccc14 ; Cc1ccccc1-c1cc2c3c(c1)N(c1cc4c(cc1C)C(C)(C)CCC4(C)C)c1c(ccc4c1sc1cccc(C(C)(C)C)c14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4sc5cccc(C(C)(C)C)c5c4cc1B3c1cc3c(cc1N2c1ccc2c(c1)C(C)(C)CCC2(C)C)C(C)(C)CCC3(C)C]

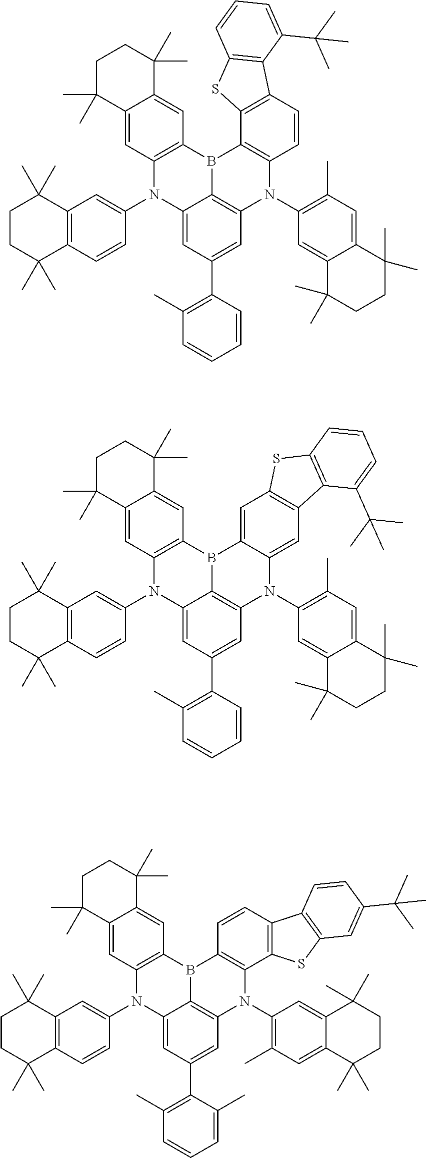 [SMILES: Cc1ccccc1-c1cc2c3c(c1)N(c1cc4c(cc1C)C(C)(C)CCC4(C)C)c1ccc4c(sc5cccc(C(C)(C)C)c54)c1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1cccc(C(C)(C)C)c14 ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5cc(C(C)(C)C)ccc54)c31)C(C)(C)CCC2(C)C]

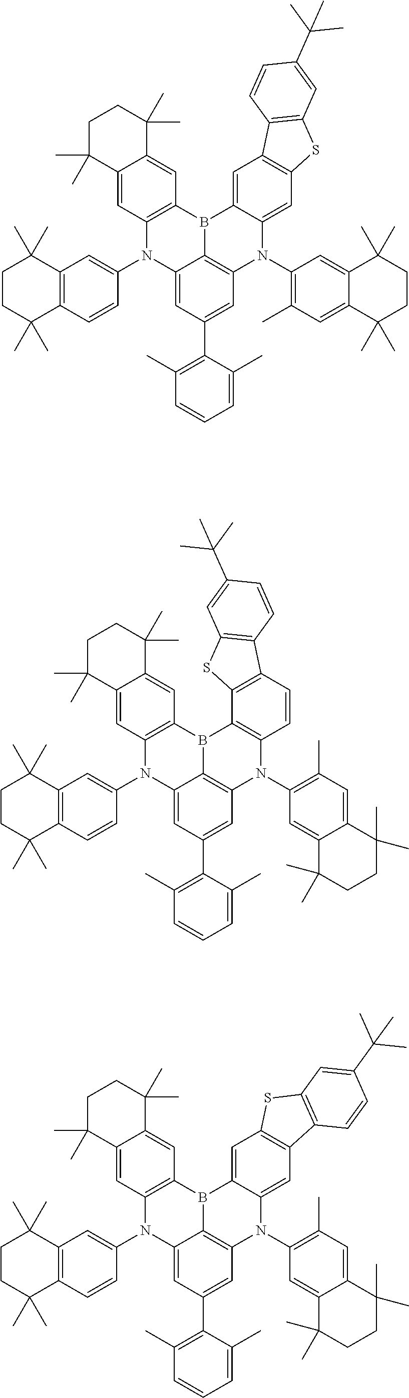 [SMILES: Cc1cc2c(cc1N1c3cc4sc5cc(C(C)(C)C)ccc5c4cc3B3c4cc5c(cc4N(c4ccc6c(c4)C(C)(C)CCC6(C)C)c4cc(-c6c(C)cccc6C)cc1c43)C(C)(C)CCC5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3sc3cc(C(C)(C)C)ccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)sc1cc(C(C)(C)C)ccc14)C(C)(C)CCC2(C)C]

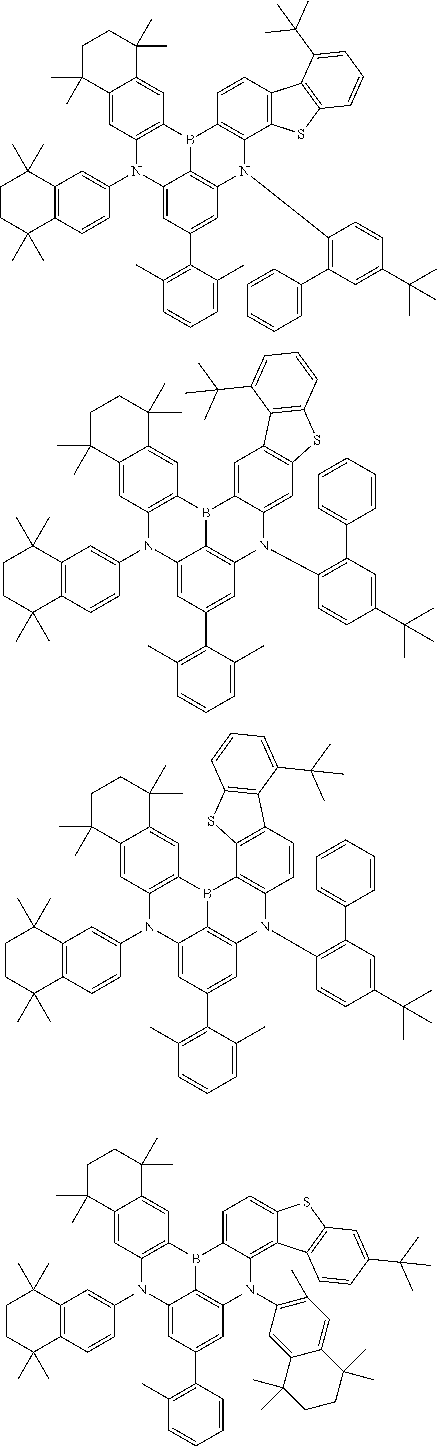

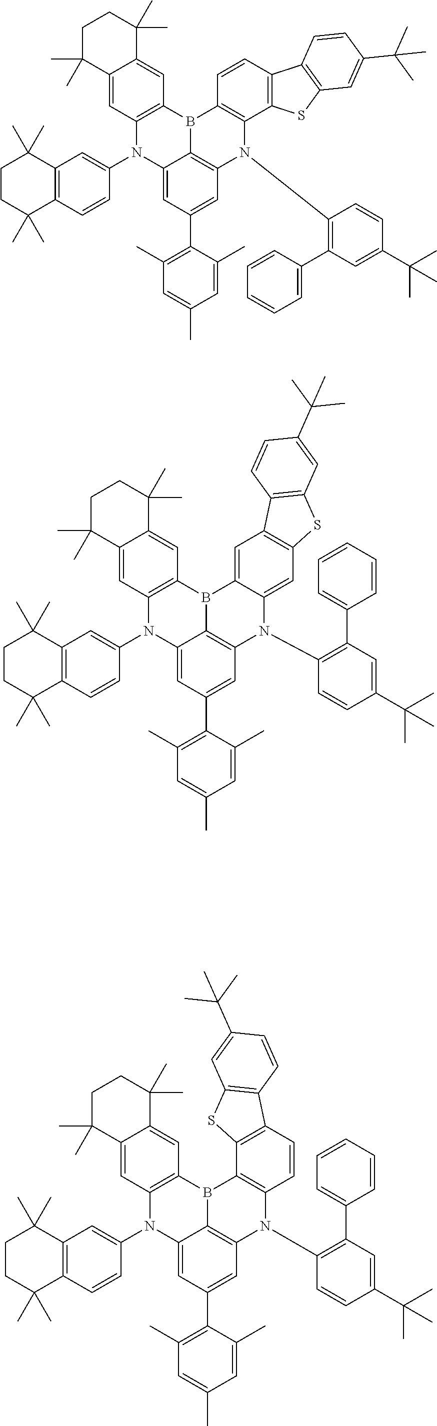 [SMILES: Cc1cc(C)c(-c2cc3c4c(c2)N(c2ccc(C(C)(C)C)cc2-c2ccccc2)c2c(ccc5c2sc2cc(C(C)(C)C)ccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6cc(C(C)(C)C)ccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2ccc5c(sc6cc(C(C)(C)C)ccc65)c2B4c2cc4c(cc2N3c2ccc3c(c2)C(C)(C)CCC3(C)C)C(C)(C)CCC4(C)C)c(C)c1]

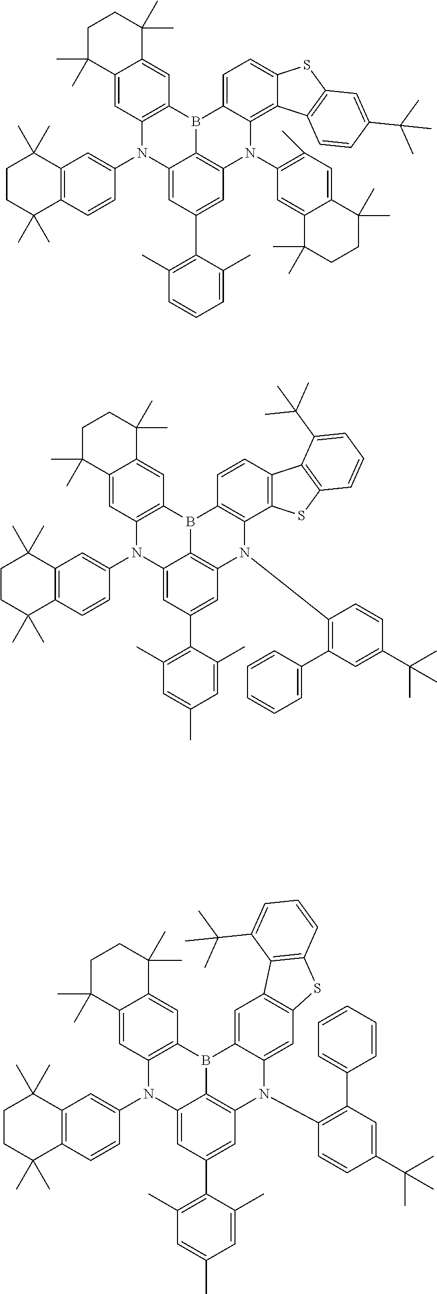 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4sc5cc(C(C)(C)C)ccc5c4c31)C(C)(C)CCC2(C)C ; Cc1cc(C)c(-c2cc3c4c(c2)N(c2ccc(C(C)(C)C)cc2-c2ccccc2)c2c(ccc5c2sc2cccc(C(C)(C)C)c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6cccc(C(C)(C)C)c6c5cc2B4c2cc4c(cc2N3c2ccc3c(c2)C(C)(C)CCC3(C)C)C(C)(C)CCC4(C)C)c(C)c1]

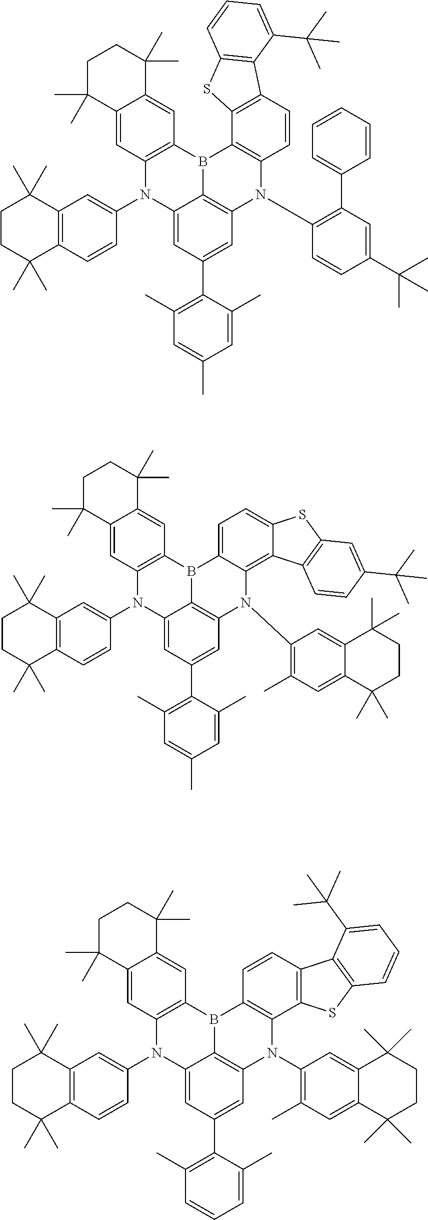 [SMILES: Cc1cc(C)c(-c2cc3c4c(c2)N(c2ccc(C(C)(C)C)cc2-c2ccccc2)c2ccc5c(sc6cccc(C(C)(C)C)c65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5sc6cc(C(C)(C)C)ccc6c25)B4c2cc4c(cc2N3c2ccc3c(c2)C(C)(C)CCC3(C)C)C(C)(C)CCC4(C)C)c(C)c1 ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5cccc(C(C)(C)C)c54)c31)C(C)(C)CCC2(C)C]

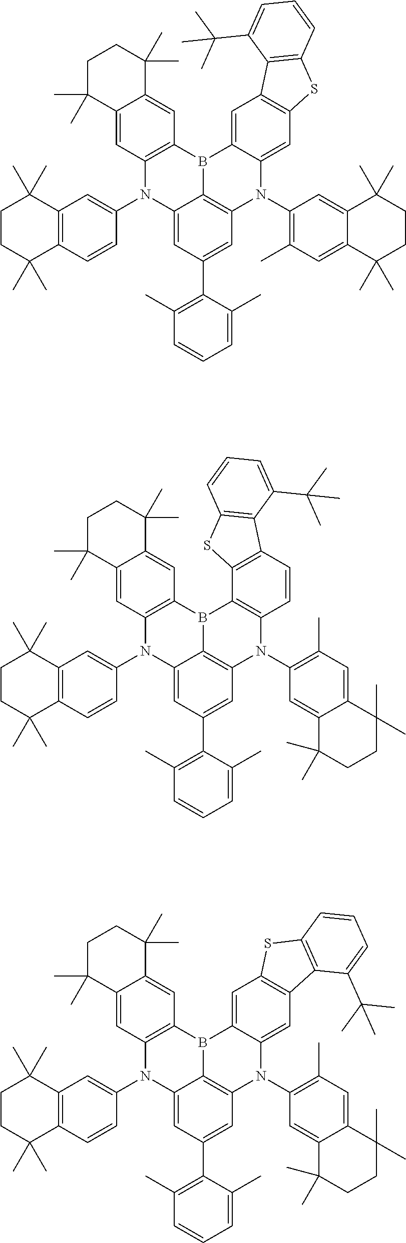 [SMILES: Cc1cc2c(cc1N1c3cc4sc5cccc(C(C)(C)C)c5c4cc3B3c4cc5c(cc4N(c4ccc6c(c4)C(C)(C)CCC6(C)C)c4cc(-c6c(C)cccc6C)cc1c43)C(C)(C)CCC5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3sc3cccc(C(C)(C)C)c31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)sc1cccc(C(C)(C)C)c14)C(C)(C)CCC2(C)C]

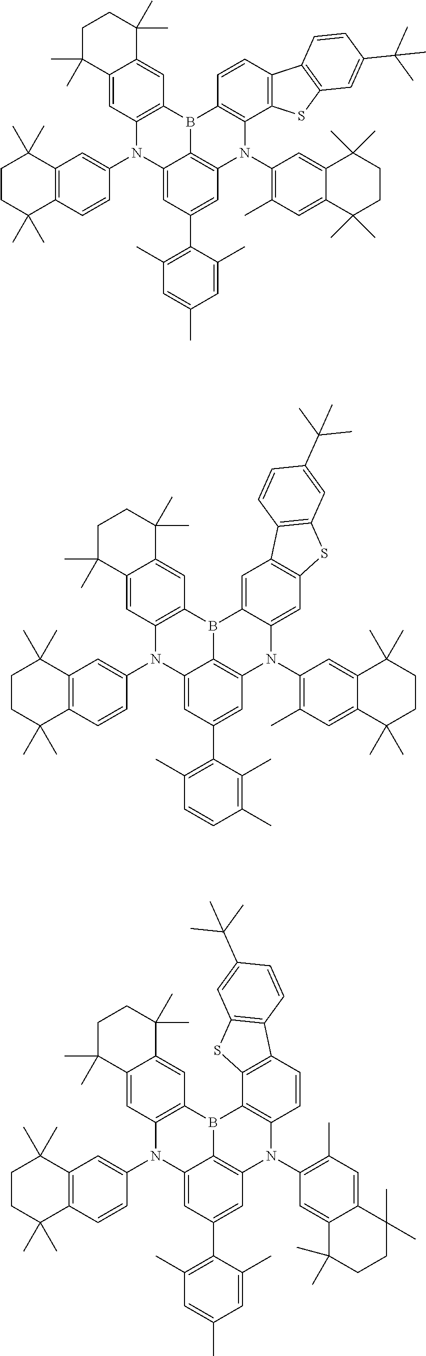 [SMILES: Cc1cc(C)c(-c2cc3c4c(c2)N(c2cc5c(cc2C)C(C)(C)CCC5(C)C)c2c(ccc5c2sc2cc(C(C)(C)C)ccc25)B4c2cc4c(cc2N3c2ccc3c(c2)C(C)(C)CCC3(C)C)C(C)(C)CCC4(C)C)c(C)c1 ; Cc1cc2c(cc1N1c3cc4sc5cc(C(C)(C)C)ccc5c4cc3B3c4cc5c(cc4N(c4ccc6c(c4)C(C)(C)CCC6(C)C)c4cc(-c6c(C)ccc(C)c6C)cc1c43)C(C)(C)CCC5(C)C)C(C)(C)CCC2(C)C ; Cc1cc(C)c(-c2cc3c4c(c2)N(c2cc5c(cc2C)C(C)(C)CCC5(C)C)c2ccc5c(sc6cc(C(C)(C)C)ccc65)c2B4c2cc4c(cc2N3c2ccc3c(c2)C(C)(C)CCC3(C)C)C(C)(C)CCC4(C)C)c(C)c1]

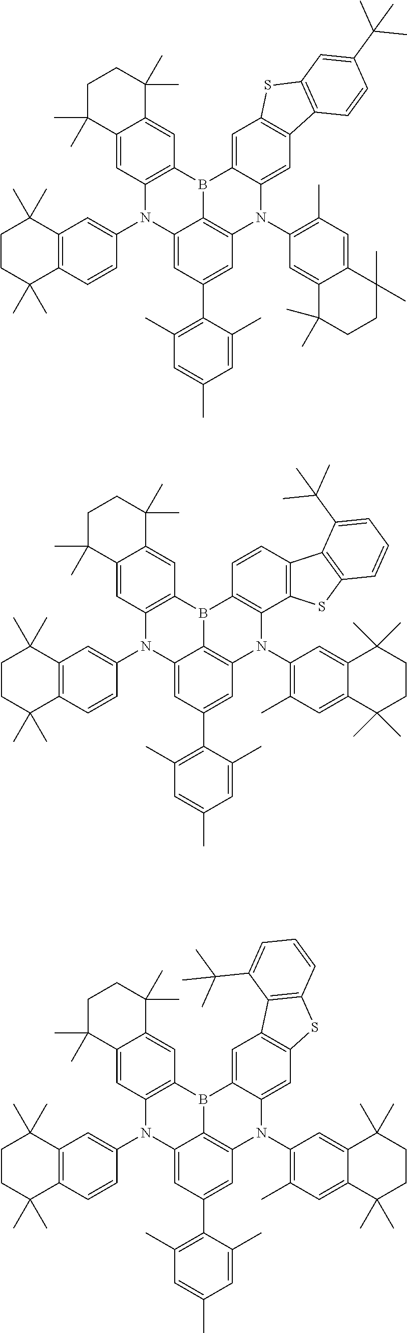 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2cc(C(C)(C)C)ccc25)c(C)c1 ; Cc1cc(C)c(-c2cc3c4c(c2)N(c2cc5c(cc2C)C(C)(C)CCC5(C)C)c2c(ccc5c2sc2cccc(C(C)(C)C)c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5sc6cccc(C(C)(C)C)c6c5cc2B4c2cc4c(cc2N3c2ccc3c(c2)C(C)(C)CCC3(C)C)C(C)(C)CCC4(C)C)c(C)c1]

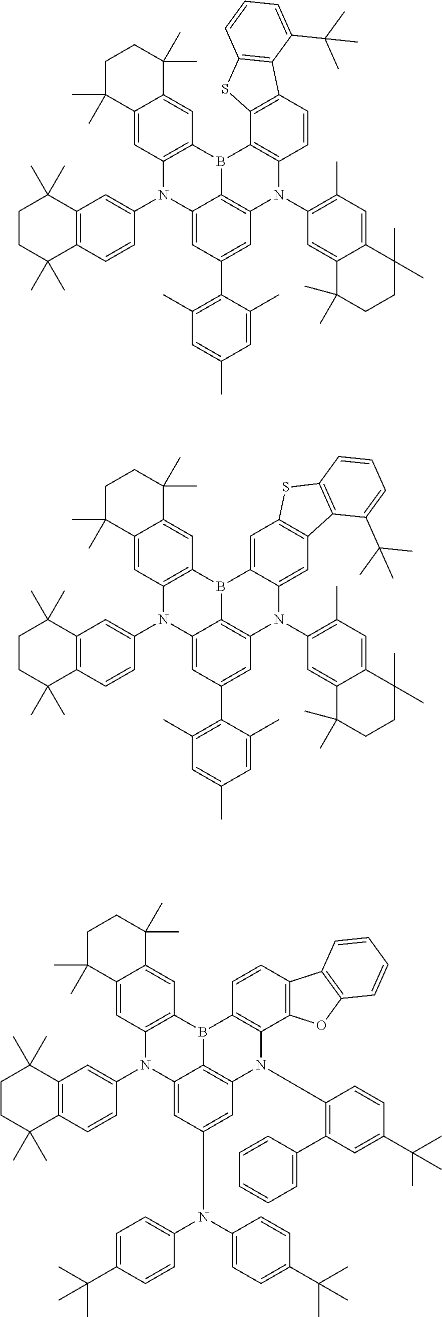 [SMILES: Cc1cc(C)c(-c2cc3c4c(c2)N(c2cc5c(cc2C)C(C)(C)CCC5(C)C)c2ccc5c(sc6cccc(C(C)(C)C)c65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2cccc(C(C)(C)C)c25)c(C)c1 ; CC(C)(C)c1ccc(N(c2ccc(C(C)(C)C)cc2)c2cc3c4c(c2)N(c2ccc(C(C)(C)C)cc2-c2ccccc2)c2c(ccc5c2oc2ccccc25)B4c2cc4c(cc2N3c2ccc3c(c2)C(C)(C)CCC3(C)C)C(C)(C)CCC4(C)C)cc1]

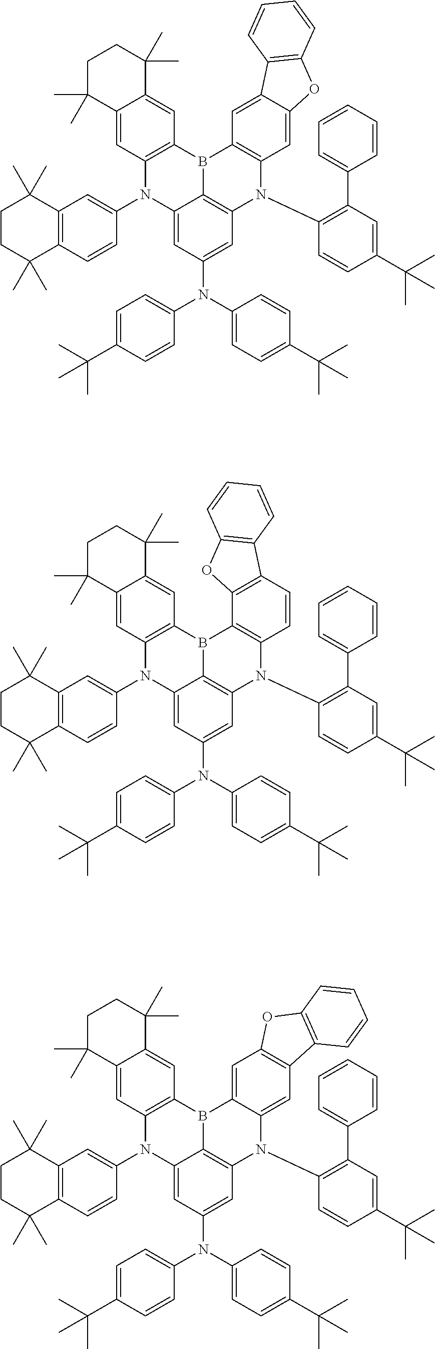 [SMILES: CC(C)(C)c1ccc(N(c2ccc(C(C)(C)C)cc2)c2cc3c4c(c2)N(c2ccc(C(C)(C)C)cc2-c2ccccc2)c2cc5oc6ccccc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2ccc5c(oc6ccccc65)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2ccccc25)cc1]

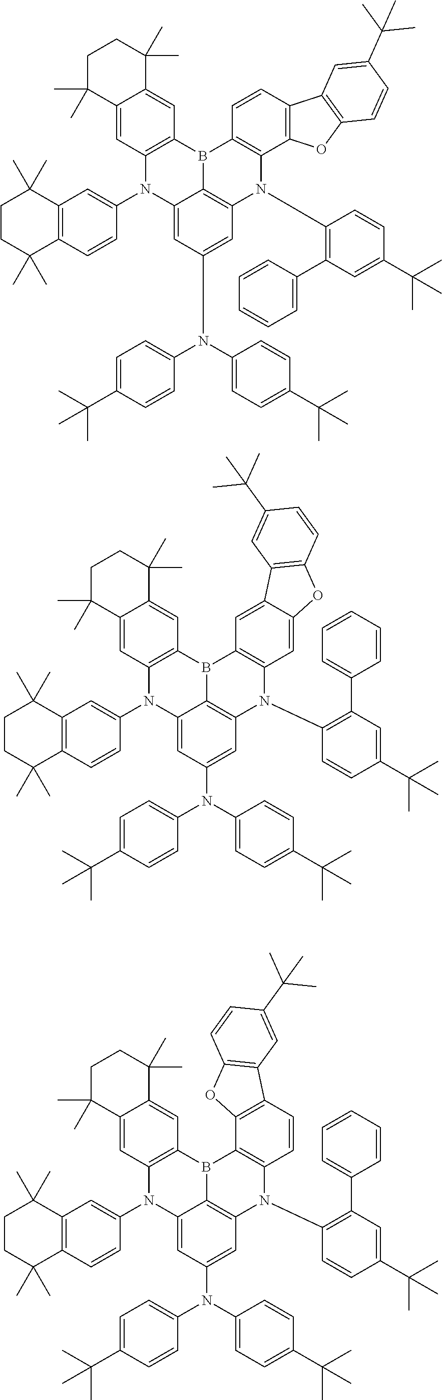

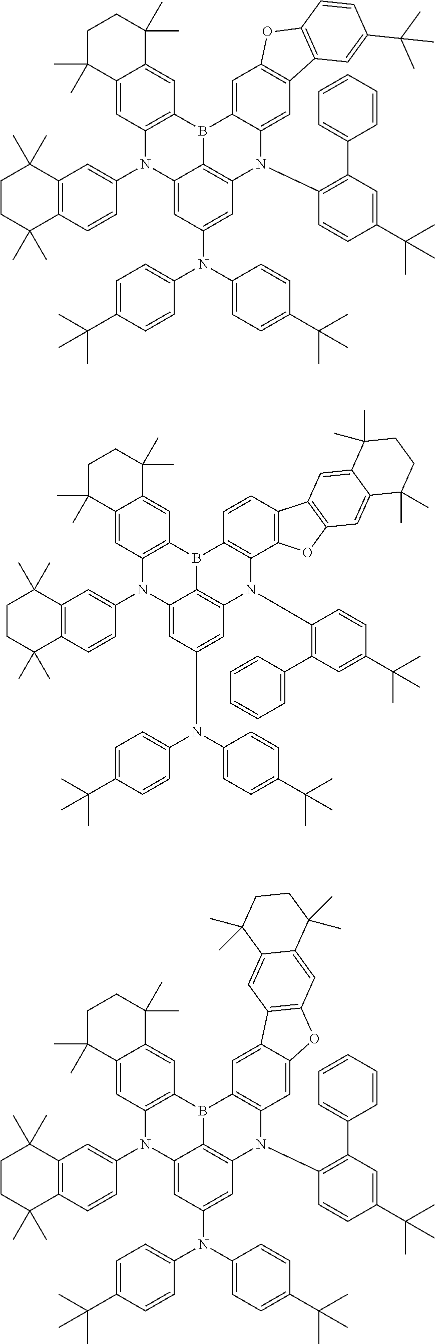

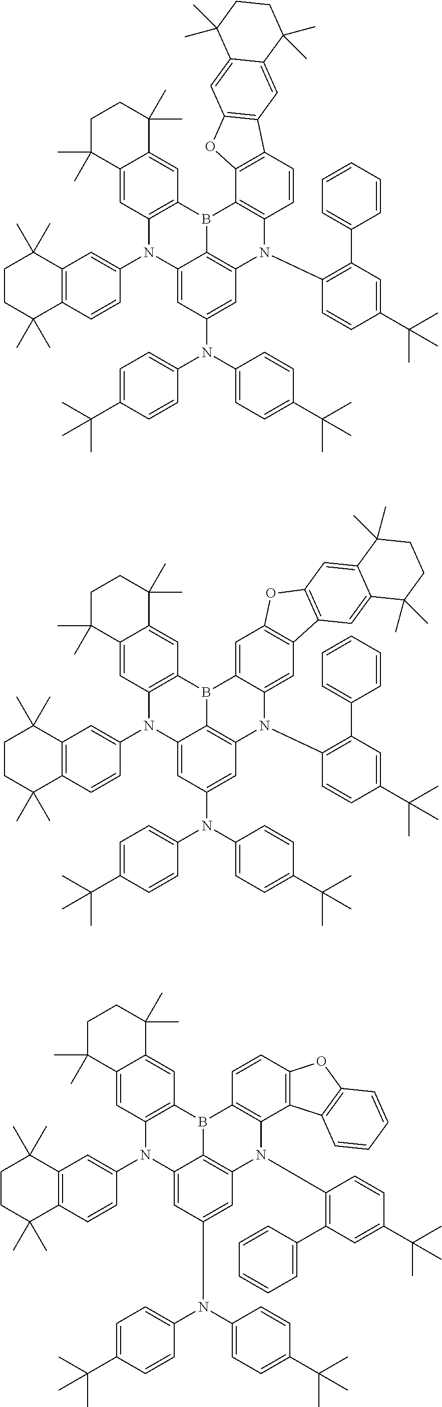

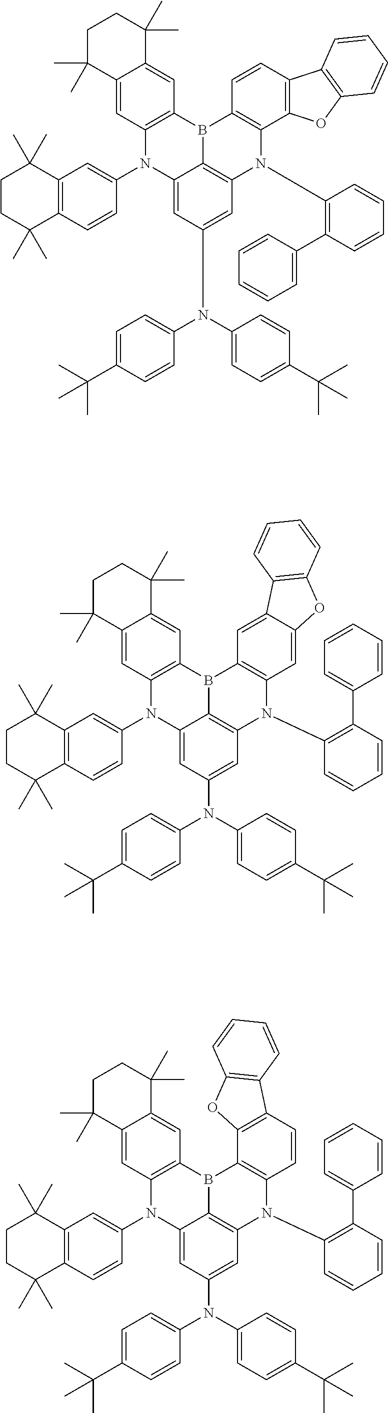 [SMILES: CC(C)(C)c1ccc(N(c2ccc(C(C)(C)C)cc2)c2cc3c4c(c2)N(c2ccccc2-c2ccccc2)c2c(ccc5c2oc2ccccc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5oc6ccccc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2ccc5c(oc6ccccc65)c2B4c2cc4c(cc2N3c2ccc3c(c2)C(C)(C)CCC3(C)C)C(C)(C)CCC4(C)C)cc1]

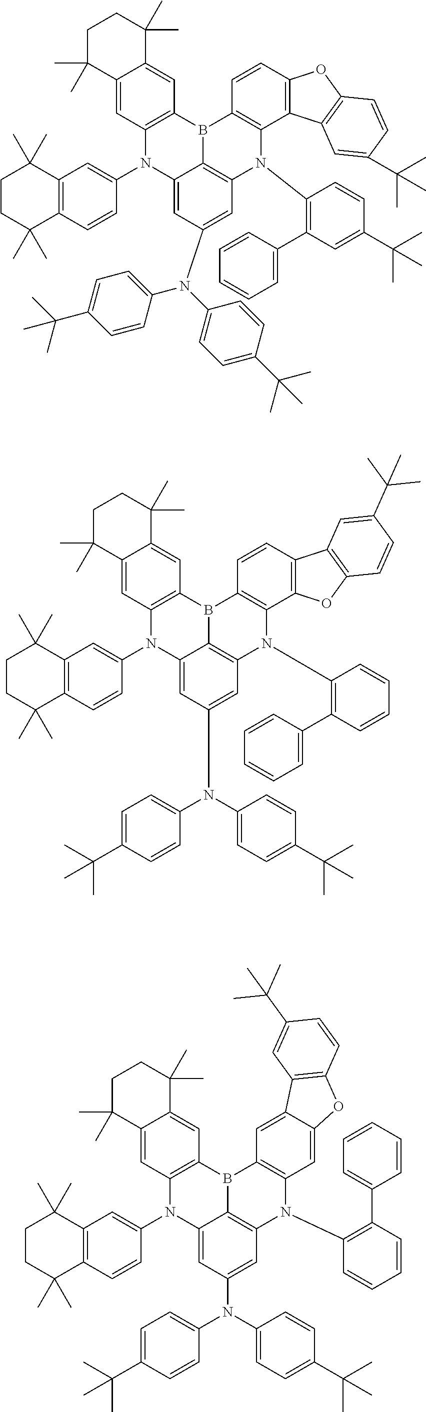 [SMILES: CC(C)(C)c1ccc(N(c2ccc(C(C)(C)C)cc2)c2cc3c4c(c2)N(c2ccc(C(C)(C)C)cc2-c2ccccc2)c2c(ccc5oc6ccc(C(C)(C)C)cc6c25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2c(ccc5c2oc2ccc(C(C)(C)C)cc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5oc6ccc(C(C)(C)C)cc6c5cc2B4c2cc4c(cc2N3c2ccc3c(c2)C(C)(C)CCC3(C)C)C(C)(C)CCC4(C)C)cc1]

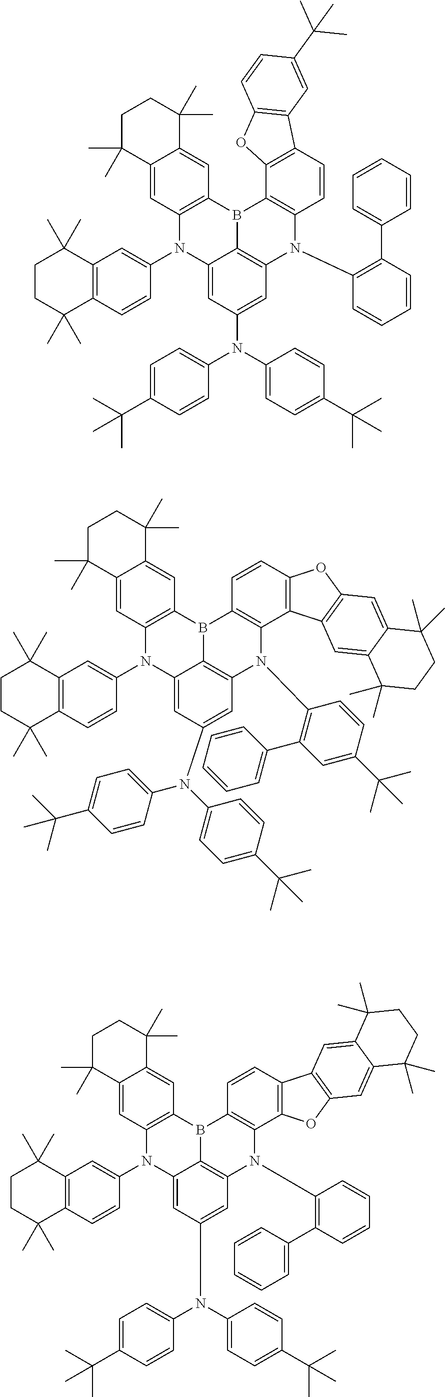

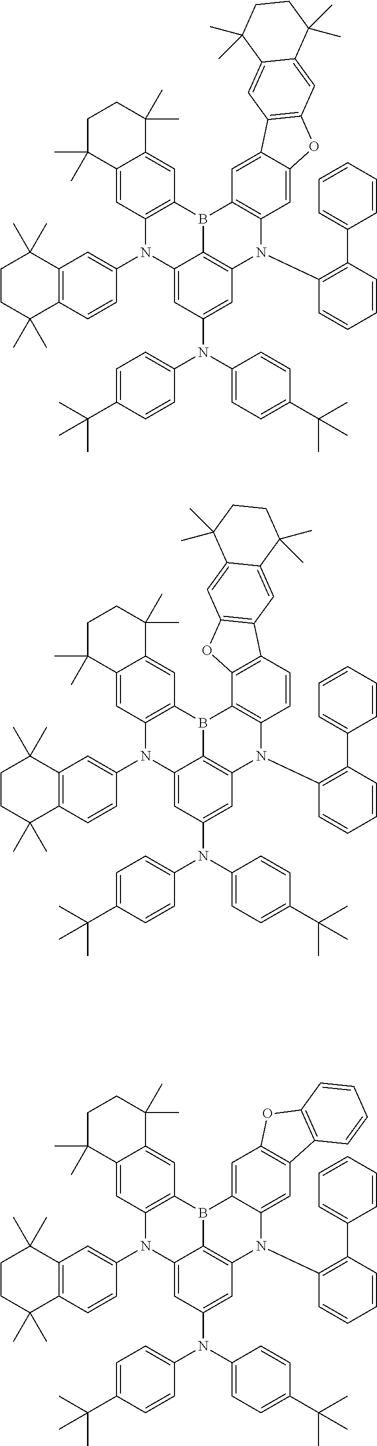 [SMILES: CC(C)(C)c1ccc(N(c2ccc(C(C)(C)C)cc2)c2cc3c4c(c2)N(c2ccccc2-c2ccccc2)c2cc5oc6cc7c(cc6c5cc2B4c2cc4c(cc2N3c2ccc3c(c2)C(C)(C)CCC3(C)C)C(C)(C)CCC4(C)C)C(C)(C)CCC7(C)C)cc1 ; CC(C)(C)c1ccc(N(c2ccc(C(C)(C)C)cc2)c2cc3c4c(c2)N(c2ccccc2-c2ccccc2)c2ccc5c(oc6cc7c(cc65)C(C)(C)CCC7(C)C)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2ccccc25)cc1]

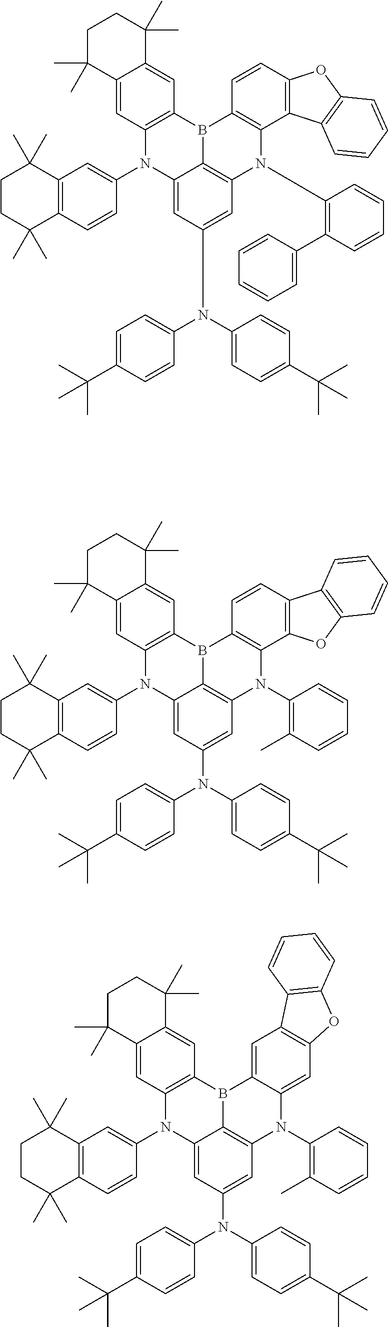 [SMILES: CC(C)(C)c1ccc(N(c2ccc(C(C)(C)C)cc2)c2cc3c4c(c2)N(c2ccccc2-c2ccccc2)c2c(ccc5oc6ccccc6c25)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(oc4ccccc43)c21 ; Cc1ccccc1N1c2cc3oc4ccccc4c3cc2B2c3cc4c(cc3N(c3ccc5c(c3)C(C)(C)CCC5(C)C)c3cc(N(c5ccc(C(C)(C)C)cc5)c5ccc(C(C)(C)C)cc5)cc1c32)C(C)(C)CCC4(C)C]

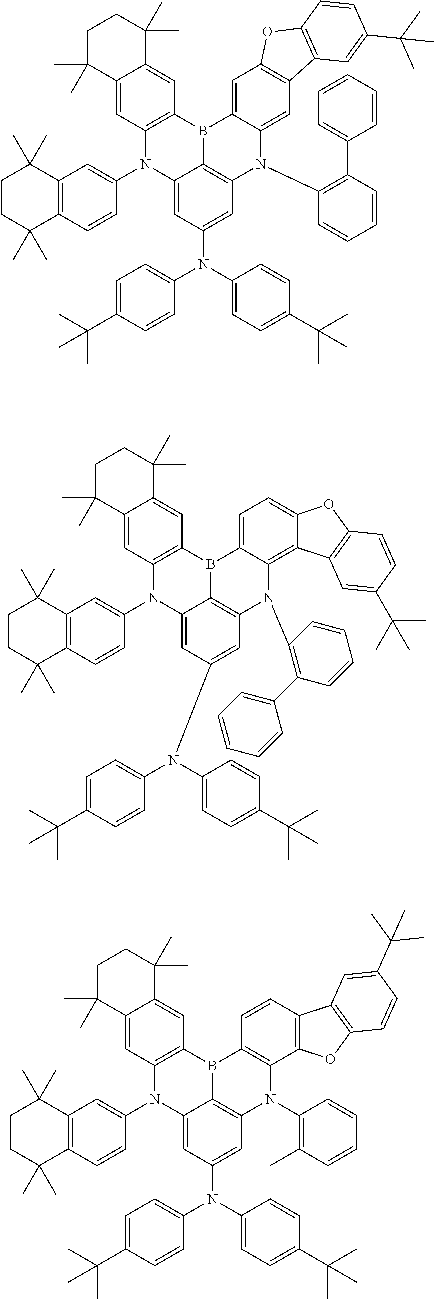 [SMILES: CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2ccc(C(C)(C)C)cc25)cc1 ; CC(C)(C)c1ccc(N(c2ccc(C(C)(C)C)cc2)c2cc3c4c(c2)N(c2ccccc2-c2ccccc2)c2c(ccc5oc6ccc(C(C)(C)C)cc6c25)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21]

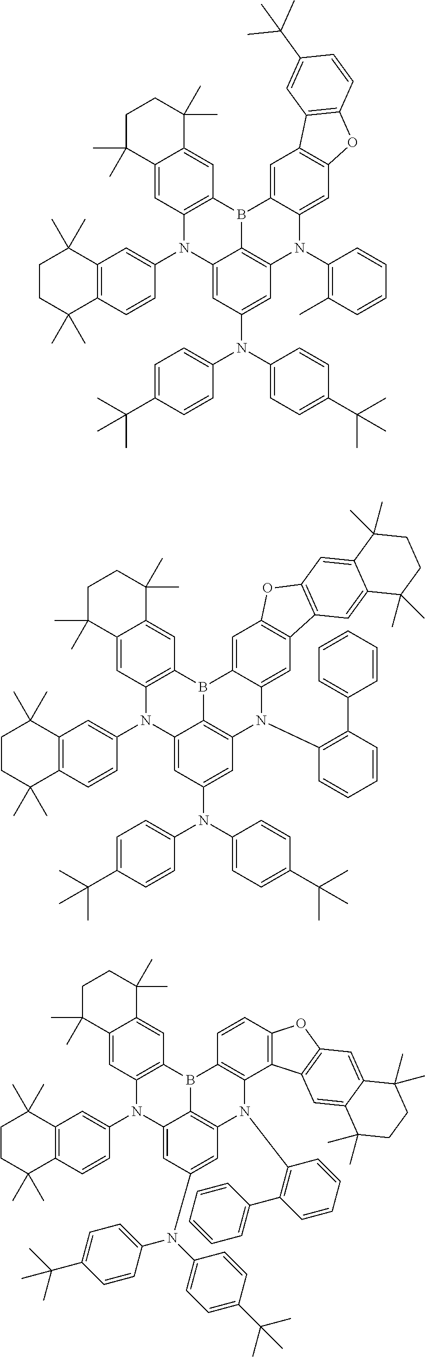 [SMILES: Cc1ccccc1N1c2cc3oc4ccc(C(C)(C)C)cc4c3cc2B2c3cc4c(cc3N(c3ccc5c(c3)C(C)(C)CCC5(C)C)c3cc(N(c5ccc(C(C)(C)C)cc5)c5ccc(C(C)(C)C)cc5)cc1c32)C(C)(C)CCC4(C)C ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)cc1 ; CC(C)(C)c1ccc(N(c2ccc(C(C)(C)C)cc2)c2cc3c4c(c2)N(c2ccccc2-c2ccccc2)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)cc1]

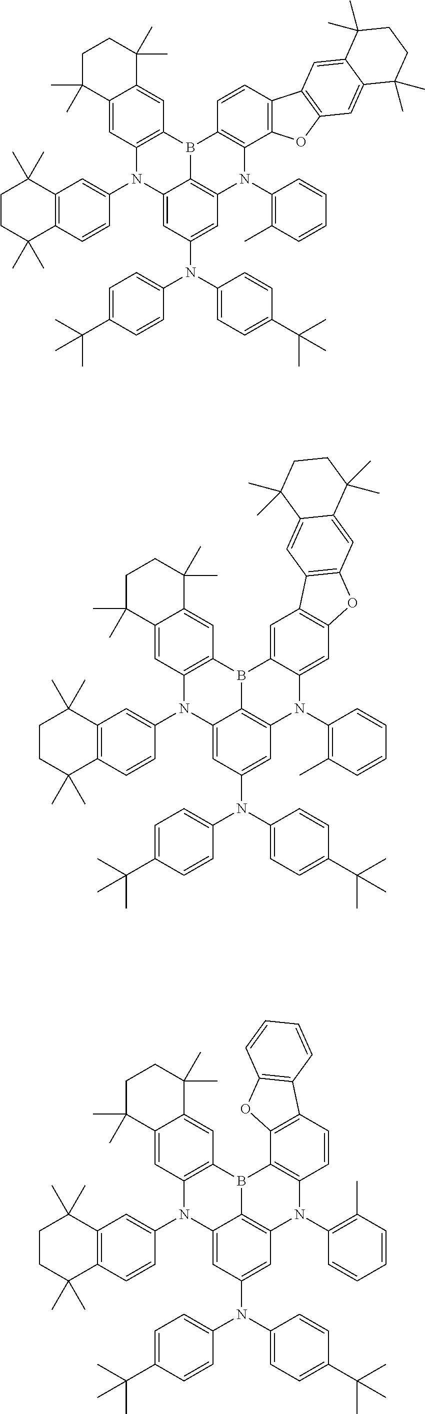 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(oc4cc5c(cc43)C(C)(C)CCC5(C)C)c21 ; Cc1ccccc1N1c2cc3oc4cc5c(cc4c3cc2B2c3cc4c(cc3N(c3ccc6c(c3)C(C)(C)CCC6(C)C)c3cc(N(c6ccc(C(C)(C)C)cc6)c6ccc(C(C)(C)C)cc6)cc1c32)C(C)(C)CCC4(C)C)C(C)(C)CCC5(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2oc2ccccc21]

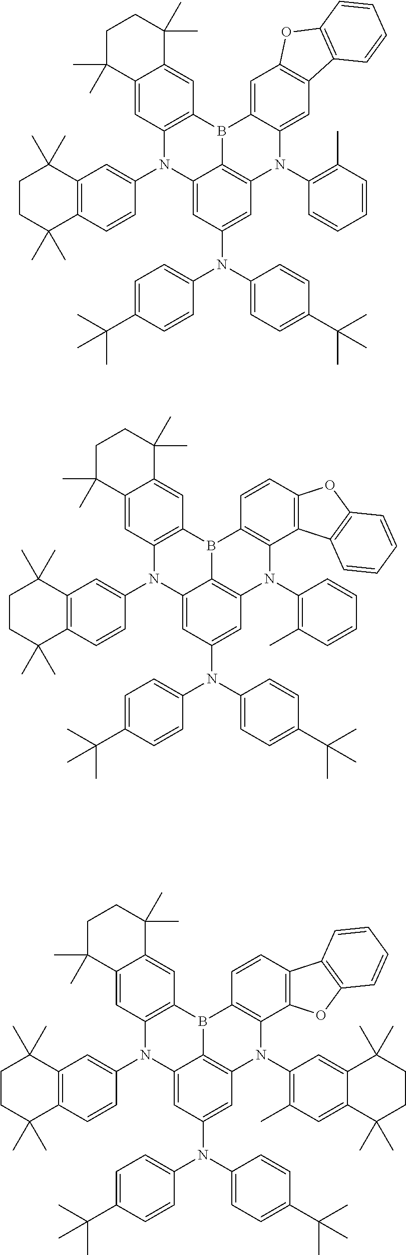 [SMILES: Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)oc1ccccc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3oc4ccccc4c3c21 ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(oc5ccccc54)c31)C(C)(C)CCC2(C)C]

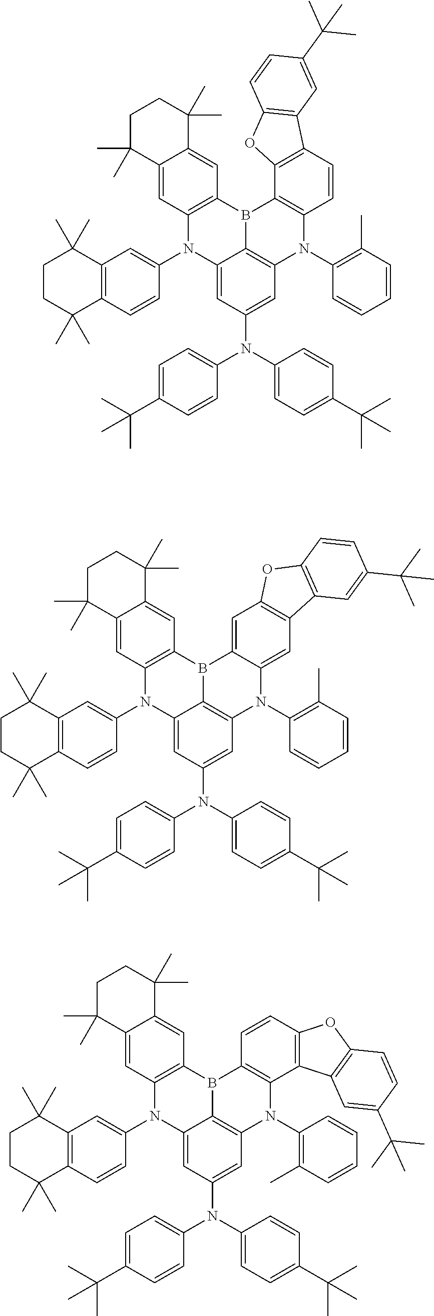 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2oc2ccc(C(C)(C)C)cc21 ; Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)oc1ccc(C(C)(C)C)cc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21]

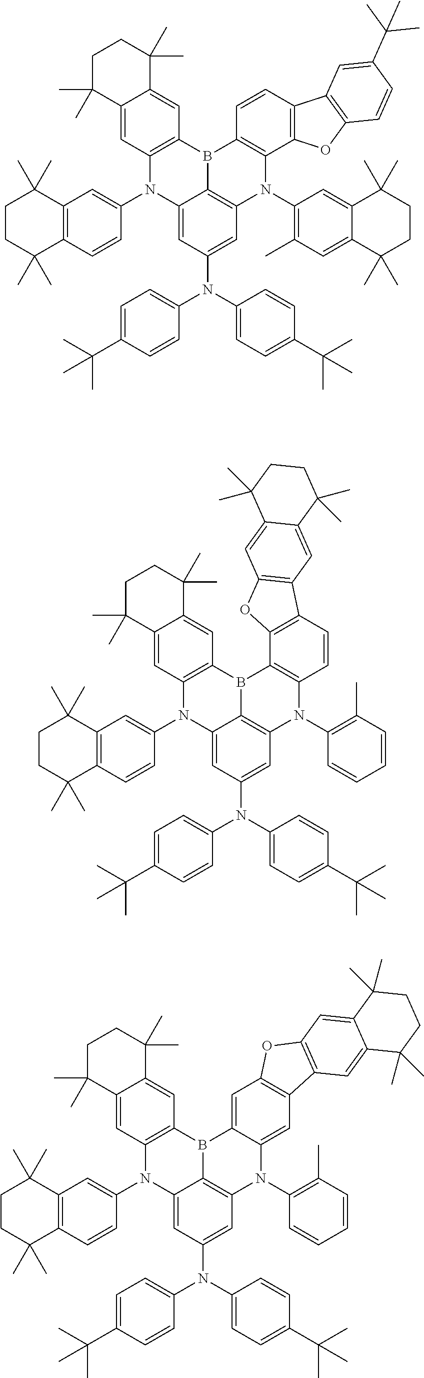 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2oc2cc3c(cc21)C(C)(C)CCC3(C)C ; Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)oc1cc2c(cc13)C(C)(C)CCC2(C)C]

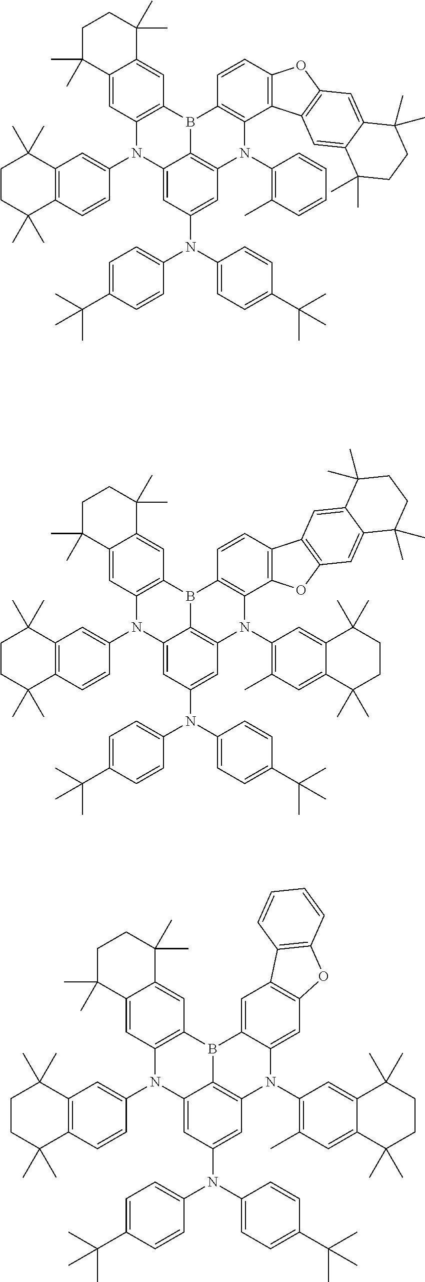 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3oc4cc5c(cc4c3c21)C(C)(C)CCC5(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c31)C(C)(C)CCC2(C)C ; Cc1cc2c(cc1N1c3cc4oc5ccccc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C]

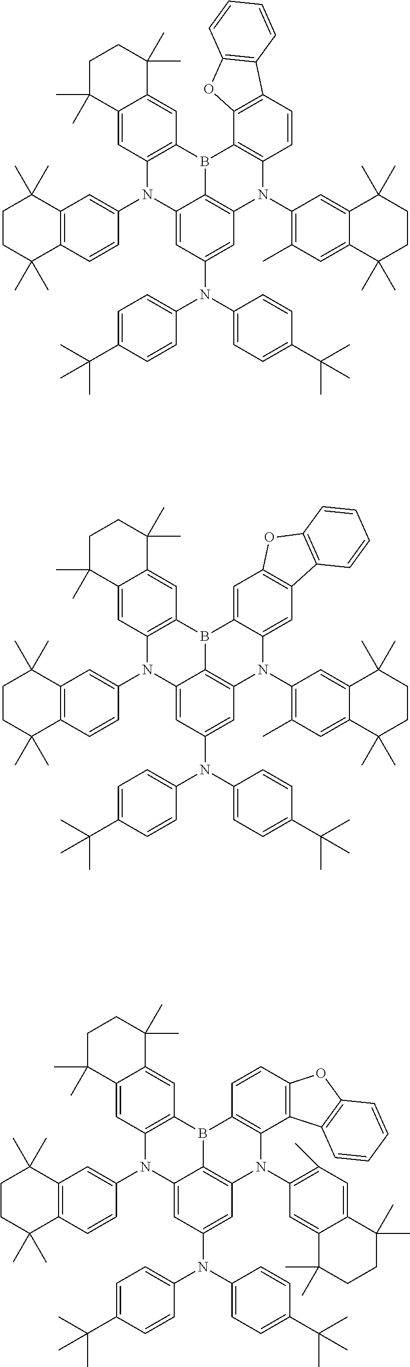 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3c1ccc1c3oc3ccccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)oc1ccccc14)C(C)(C)CCC2(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4oc5ccccc5c4c31)C(C)(C)CCC2(C)C]

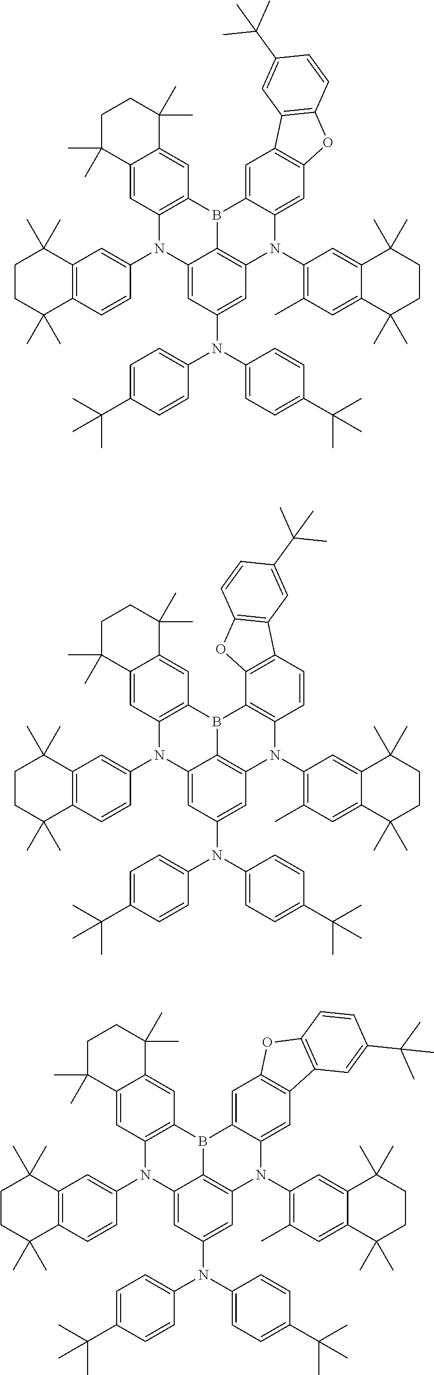

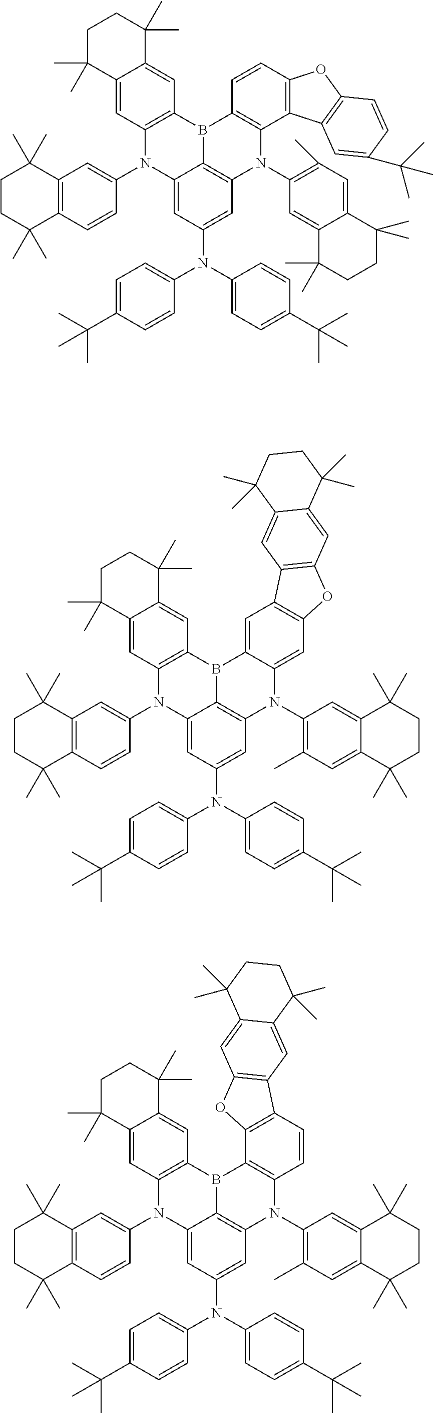

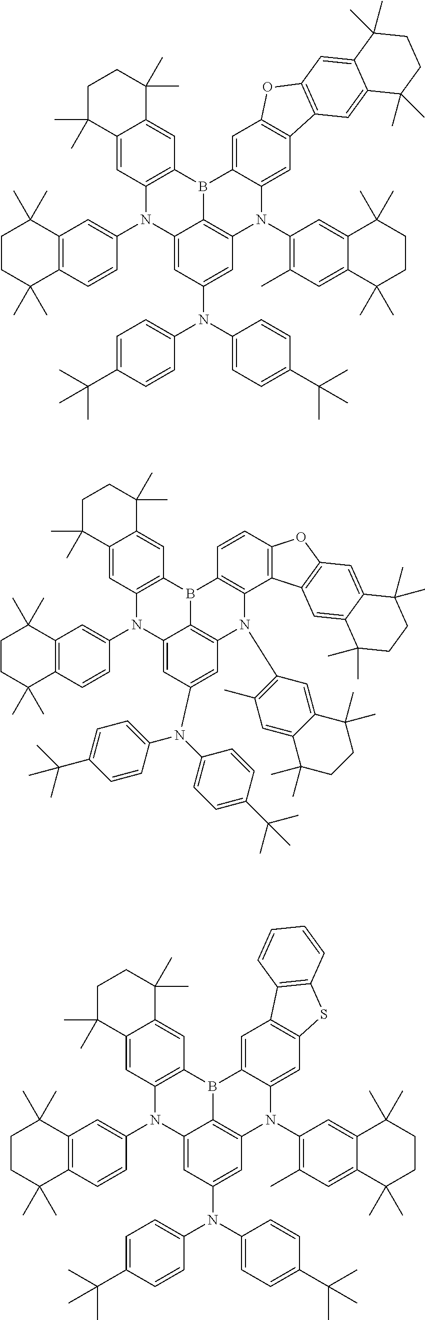

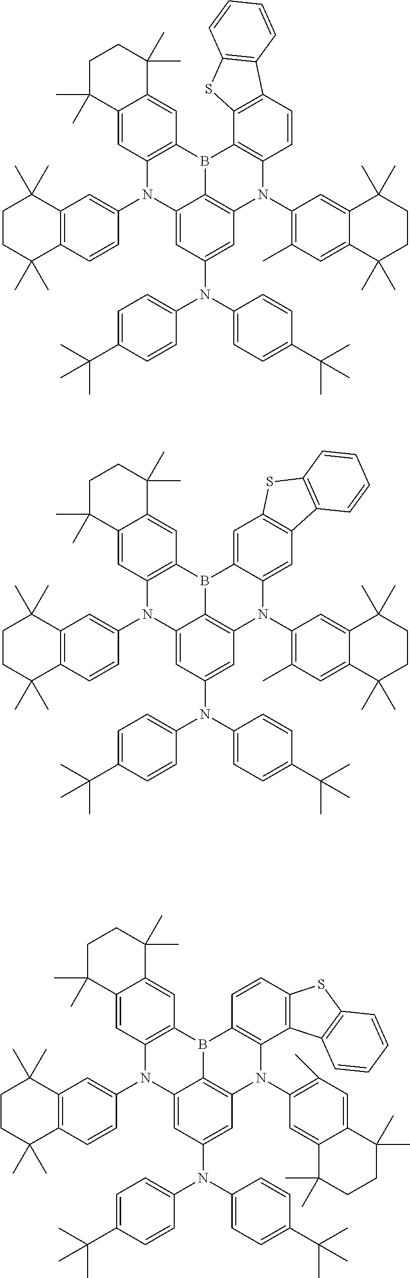 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3c1ccc1c3sc3ccccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)sc1ccccc14)C(C)(C)CCC2(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4sc5ccccc5c4c31)C(C)(C)CCC2(C)C]

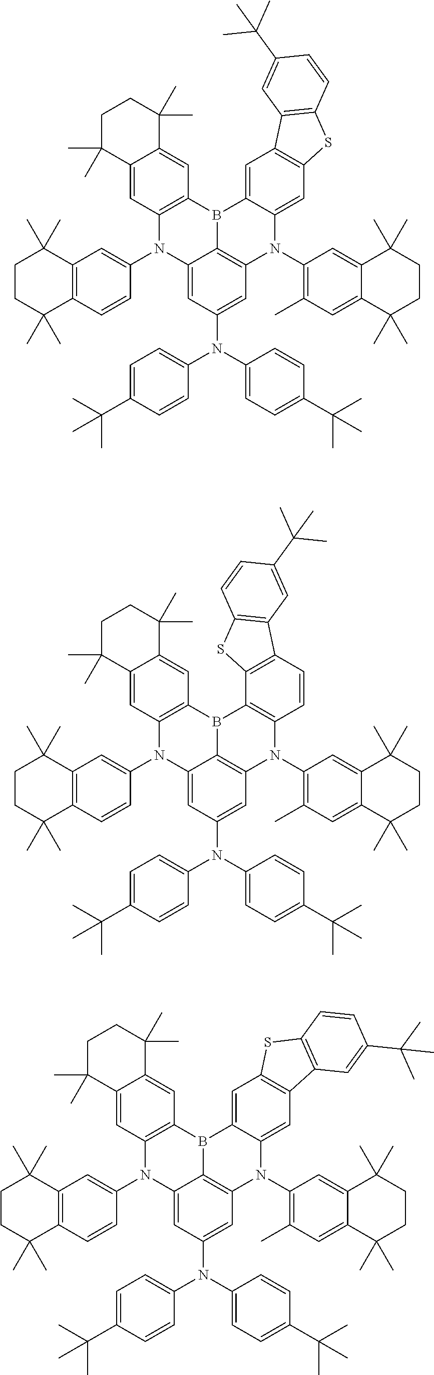

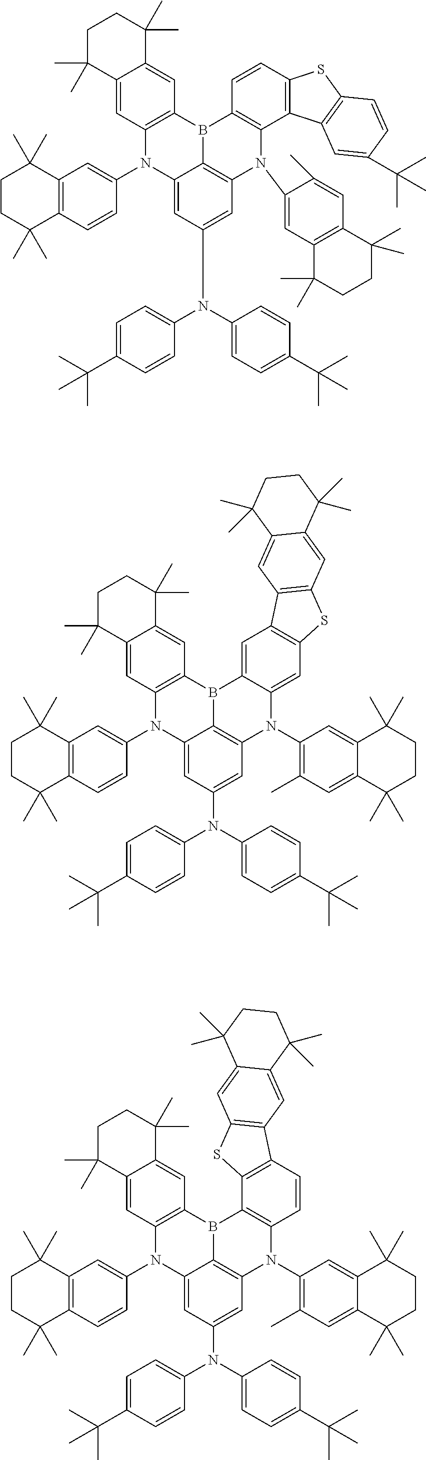

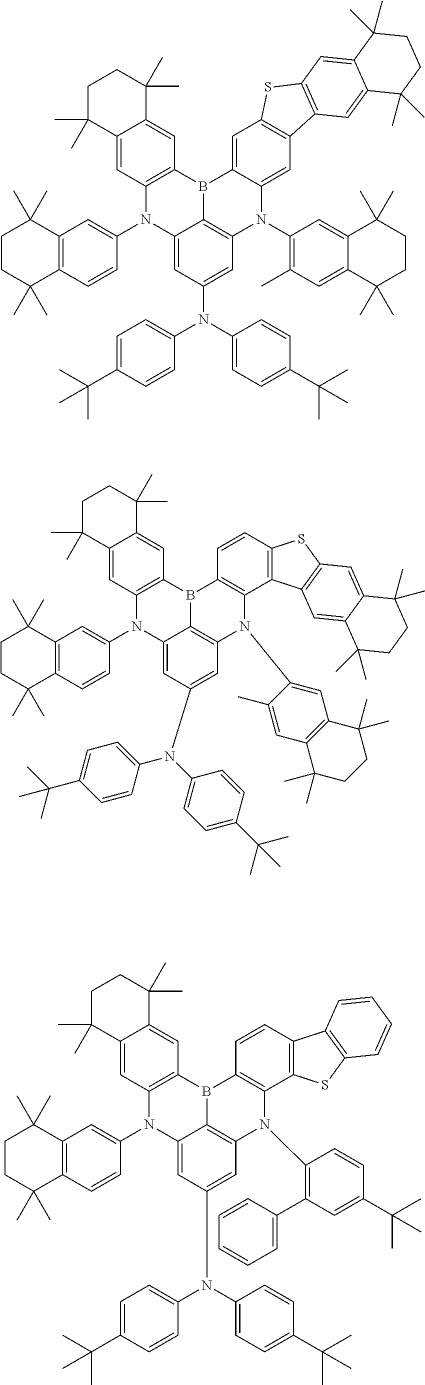

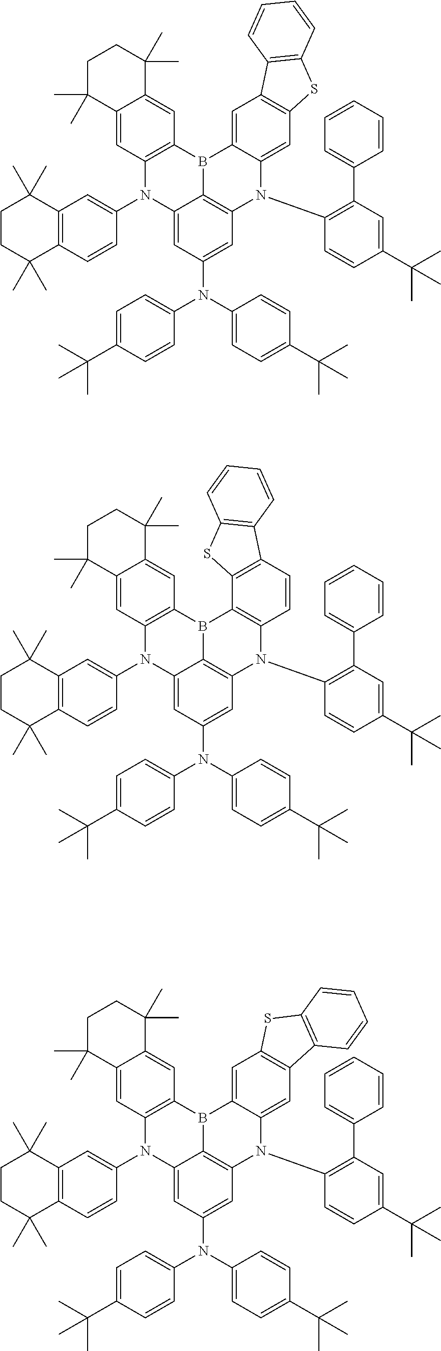 [SMILES: CC(C)(C)c1ccc(N(c2ccc(C(C)(C)C)cc2)c2cc3c4c(c2)N(c2ccc(C(C)(C)C)cc2-c2ccccc2)c2cc5sc6ccccc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2ccc5c(sc6ccccc65)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccccc25)cc1]

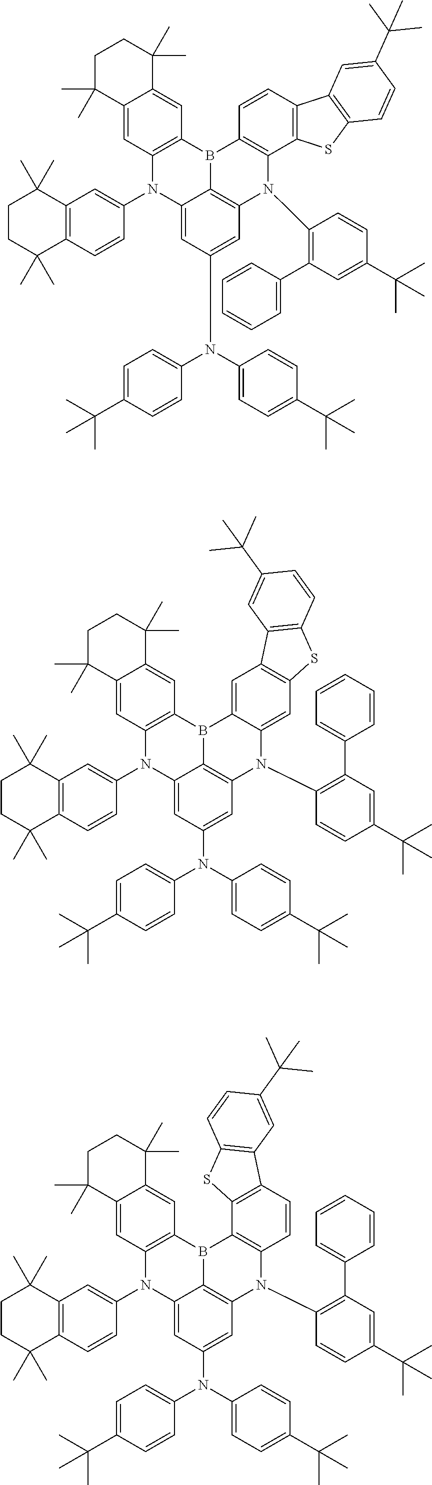

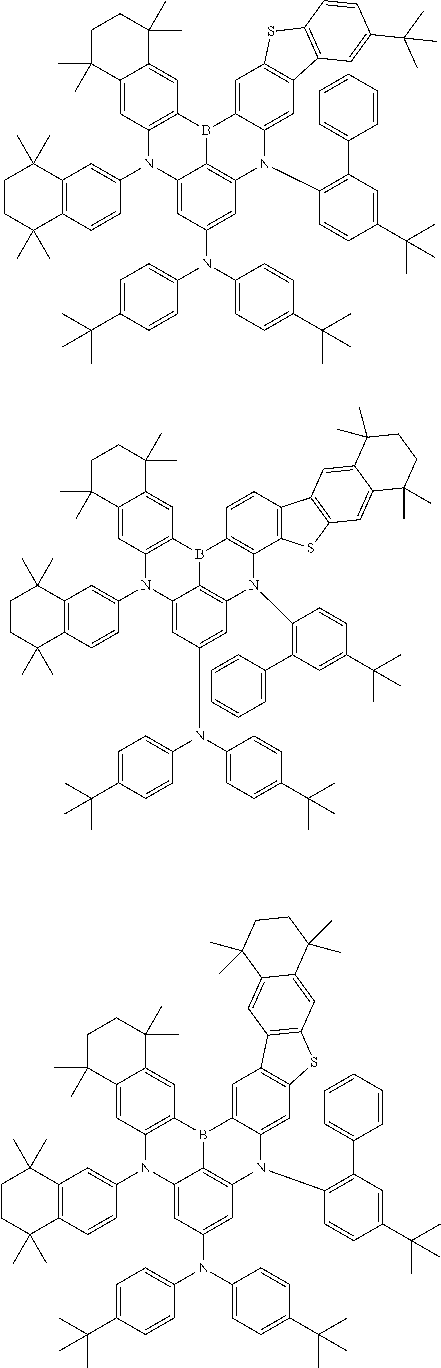

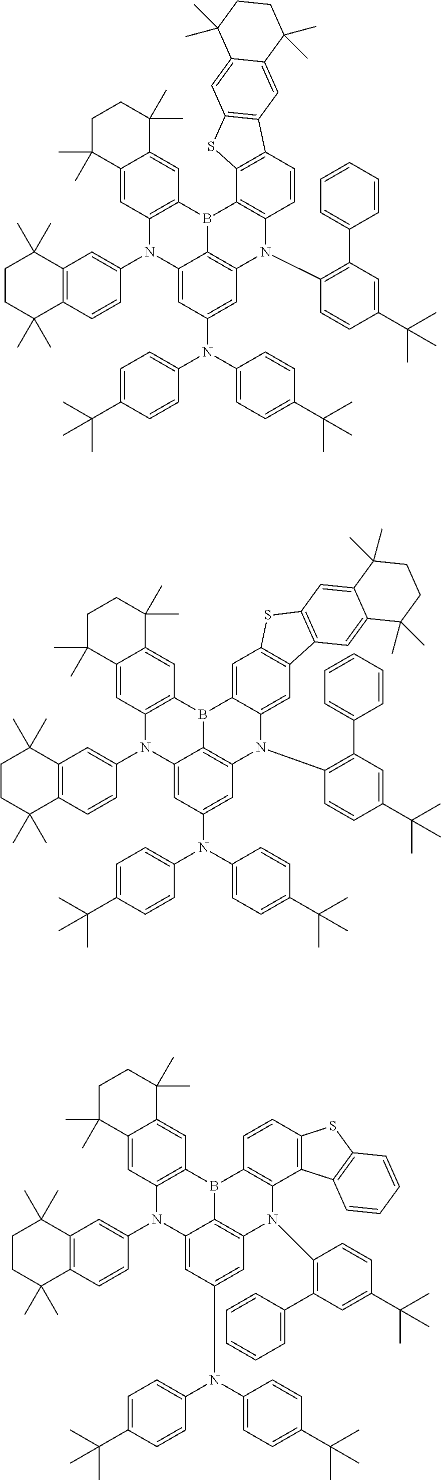

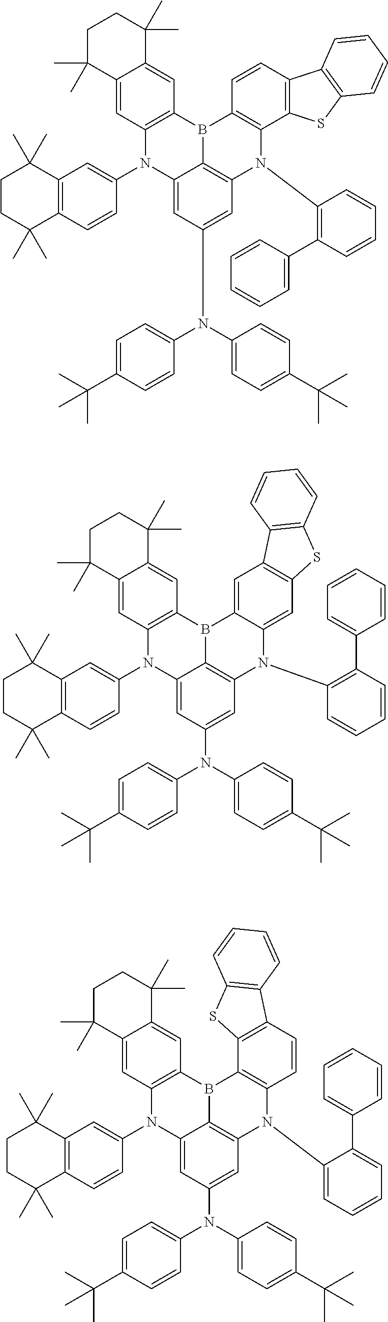 [SMILES: CC(C)(C)c1ccc(N(c2ccc(C(C)(C)C)cc2)c2cc3c4c(c2)N(c2ccccc2-c2ccccc2)c2c(ccc5c2sc2ccccc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5sc6ccccc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2ccc5c(sc6ccccc65)c2B4c2cc4c(cc2N3c2ccc3c(c2)C(C)(C)CCC3(C)C)C(C)(C)CCC4(C)C)cc1]

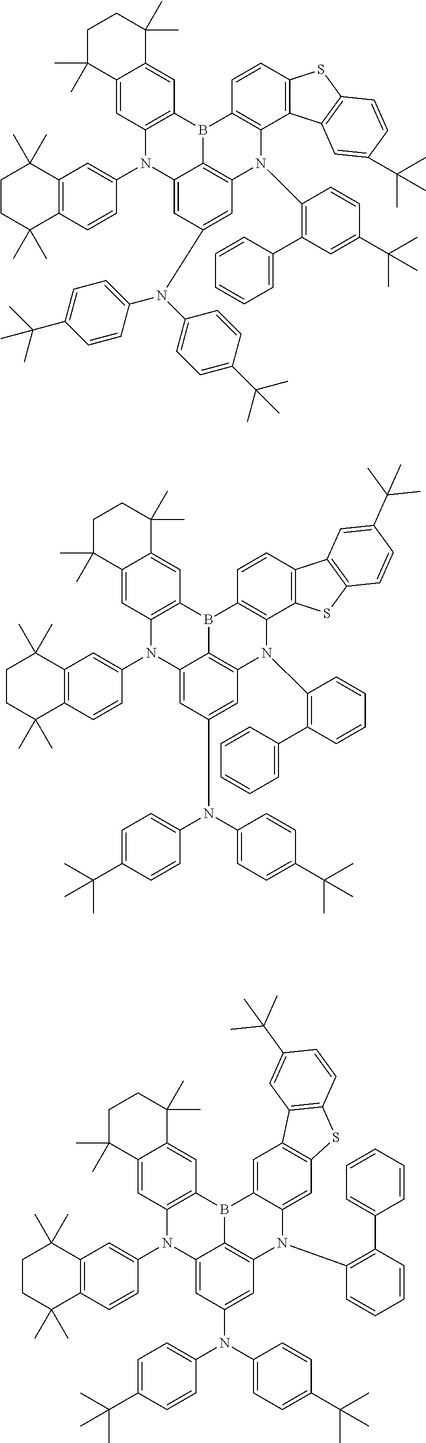 [SMILES: CC(C)(C)c1ccc(N(c2ccc(C(C)(C)C)cc2)c2cc3c4c(c2)N(c2ccc(C(C)(C)C)cc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)cc1]

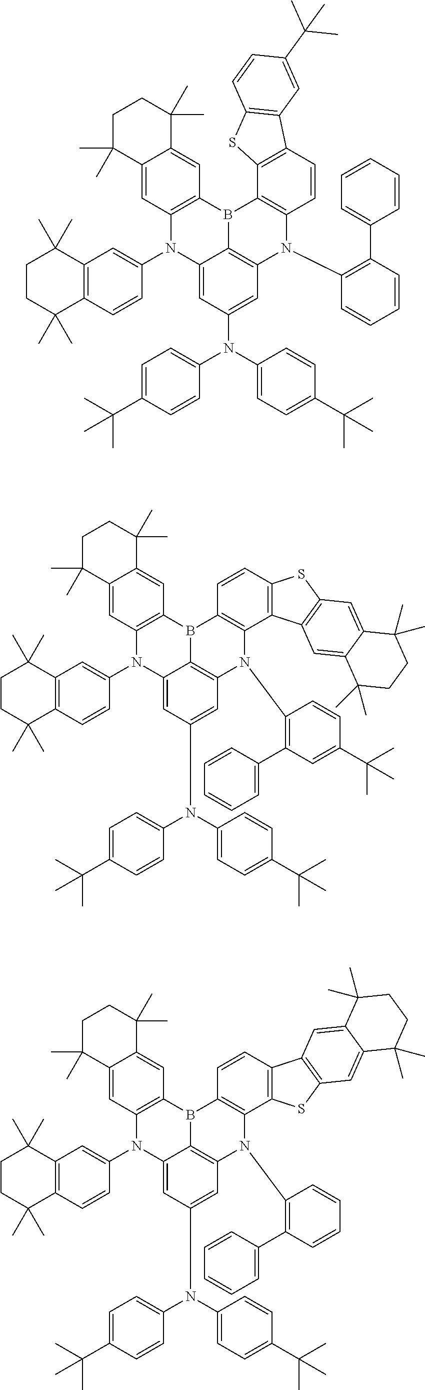

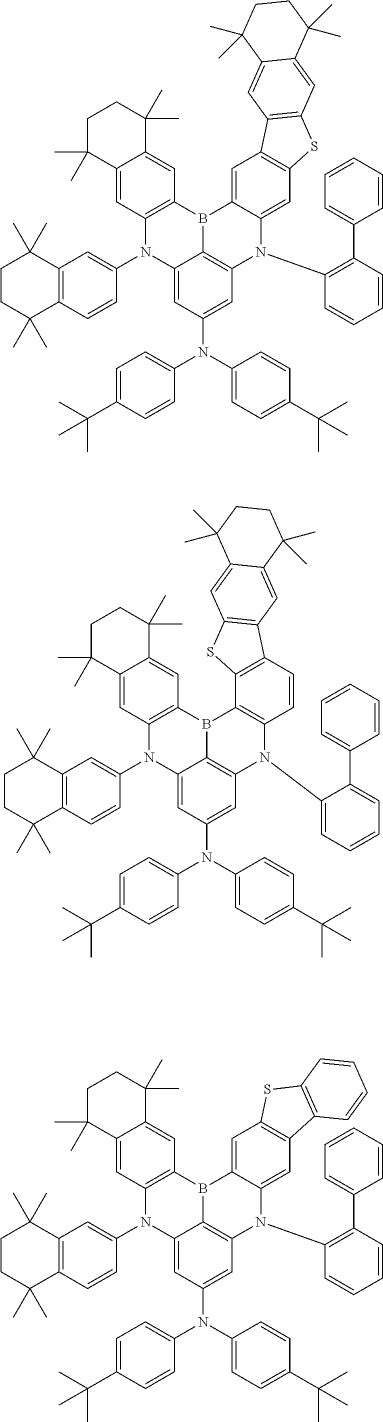 [SMILES: CC(C)(C)c1ccc(N(c2ccc(C(C)(C)C)cc2)c2cc3c4c(c2)N(c2ccccc2-c2ccccc2)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)cc1 ; CC(C)(C)c1ccc(N(c2ccc(C(C)(C)C)cc2)c2cc3c4c(c2)N(c2ccccc2-c2ccccc2)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccccc25)cc1]

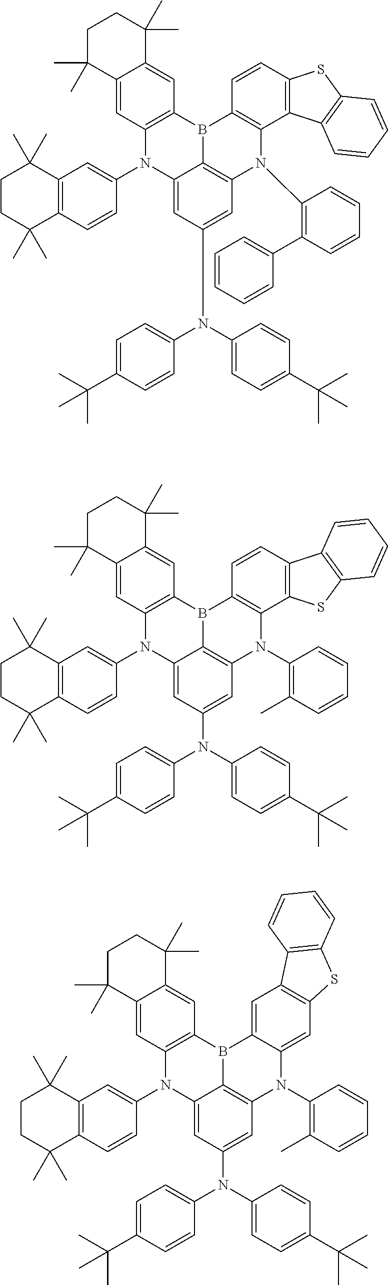

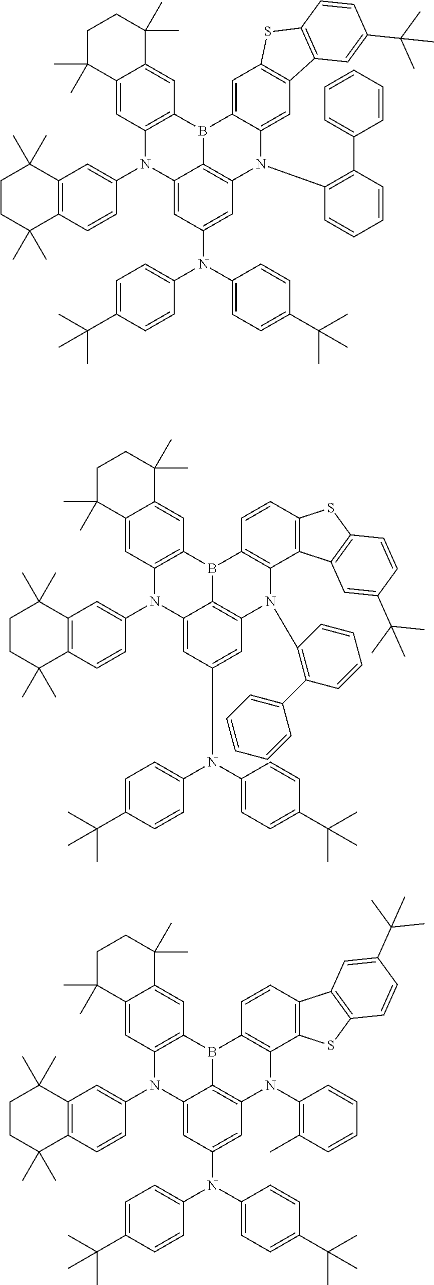 [SMILES: CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccc(C(C)(C)C)cc25)cc1 ; CC(C)(C)c1ccc(N(c2ccc(C(C)(C)C)cc2)c2cc3c4c(c2)N(c2ccccc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(sc4ccc(C(C)(C)C)cc43)c21]

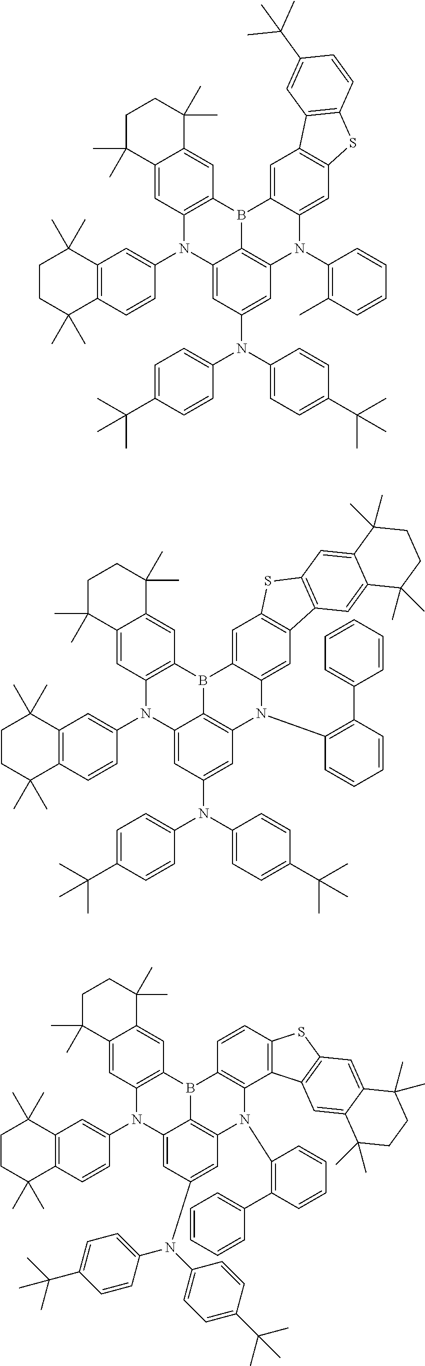 [SMILES: Cc1ccccc1N1c2cc3sc4ccc(C(C)(C)C)cc4c3cc2B2c3cc4c(cc3N(c3ccc5c(c3)C(C)(C)CCC5(C)C)c3cc(N(c5ccc(C(C)(C)C)cc5)c5ccc(C(C)(C)C)cc5)cc1c32)C(C)(C)CCC4(C)C ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)cc1 ; CC(C)(C)c1ccc(N(c2ccc(C(C)(C)C)cc2)c2cc3c4c(c2)N(c2ccccc2-c2ccccc2)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)cc1]

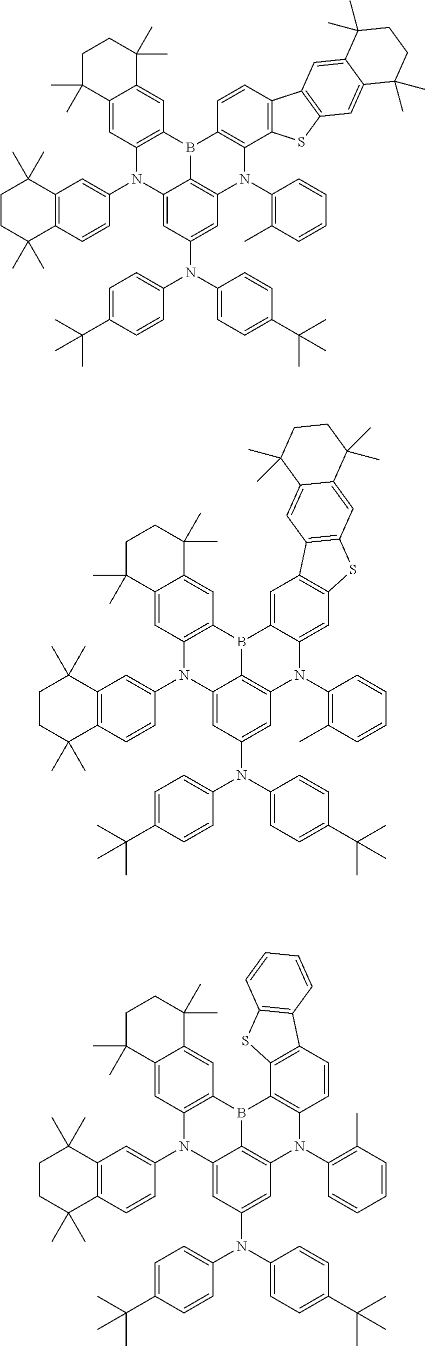 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(sc4cc5c(cc43)C(C)(C)CCC5(C)C)c21 ; Cc1ccccc1N1c2cc3sc4cc5c(cc4c3cc2B2c3cc4c(cc3N(c3ccc6c(c3)C(C)(C)CCC6(C)C)c3cc(N(c6ccc(C(C)(C)C)cc6)c6ccc(C(C)(C)C)cc6)cc1c32)C(C)(C)CCC4(C)C)C(C)(C)CCC5(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2sc2ccccc21]

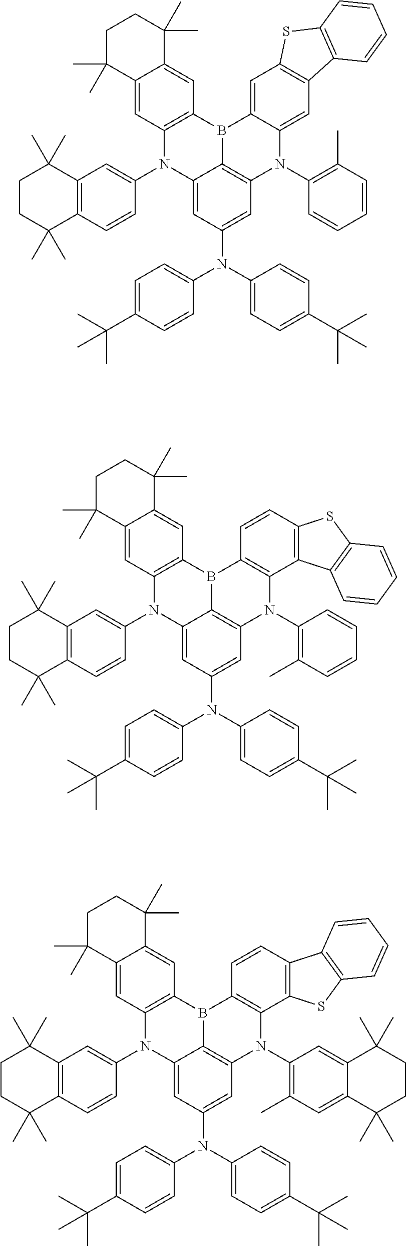 [SMILES: Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)sc1ccccc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3sc4ccccc4c3c21 ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(sc5ccccc54)c31)C(C)(C)CCC2(C)C]

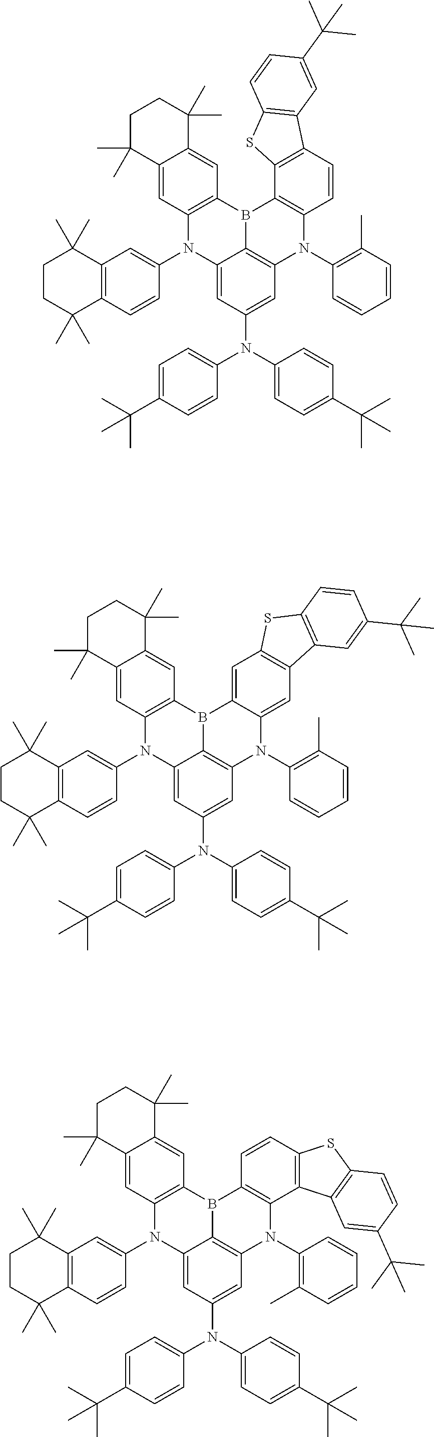 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2sc2ccc(C(C)(C)C)cc21 ; Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)sc1ccc(C(C)(C)C)cc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3sc4ccc(C(C)(C)C)cc4c3c21]

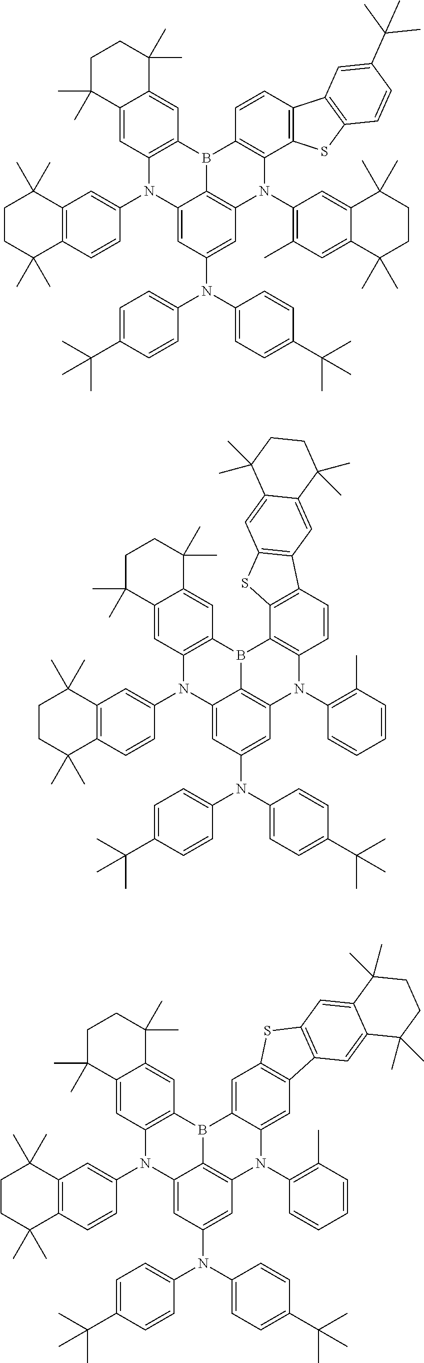 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(sc5ccc(C(C)(C)C)cc54)c31)C(C)(C)CCC2(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2sc2cc3c(cc21)C(C)(C)CCC3(C)C ; Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)sc1cc2c(cc13)C(C)(C)CCC2(C)C]

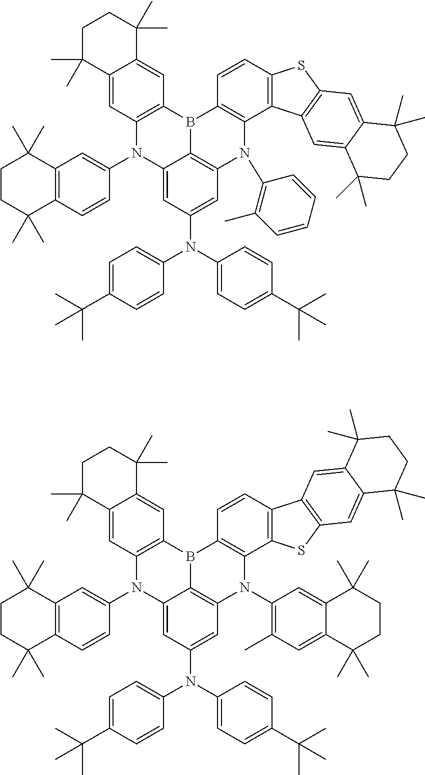 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3sc4cc5c(cc4c3c21)C(C)(C)CCC5(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(sc5cc6c(cc54)C(C)(C)CCC6(C)C)c31)C(C)(C)CCC2(C)C]

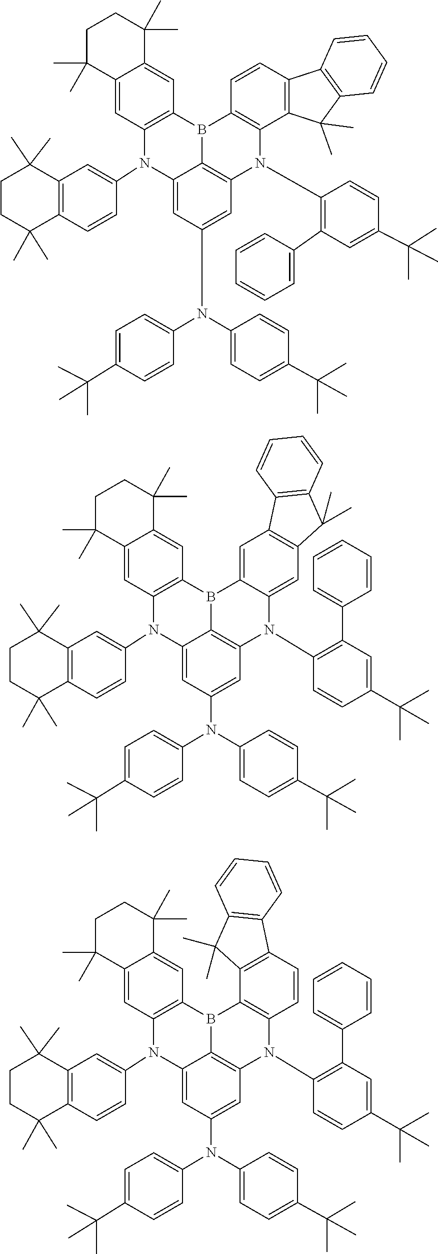

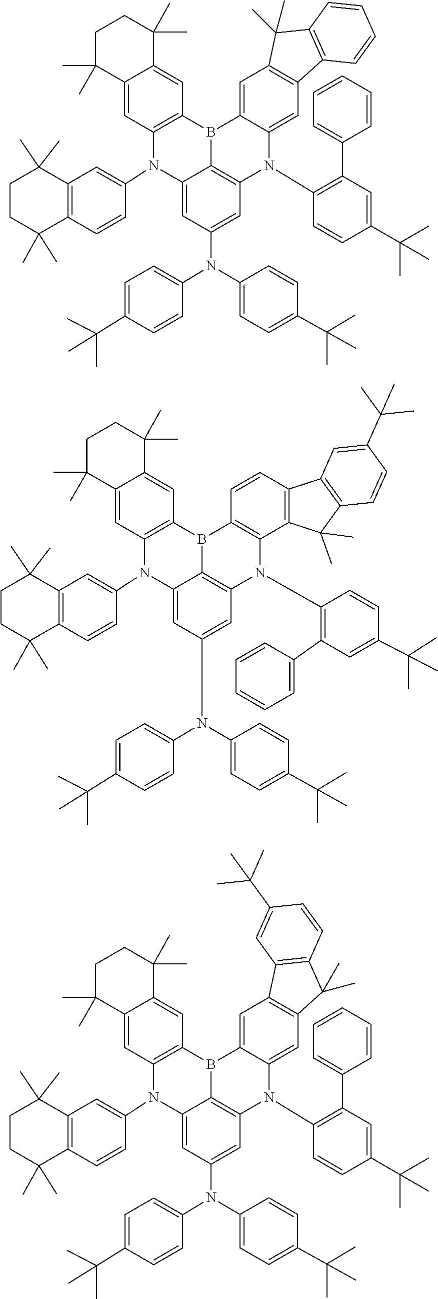

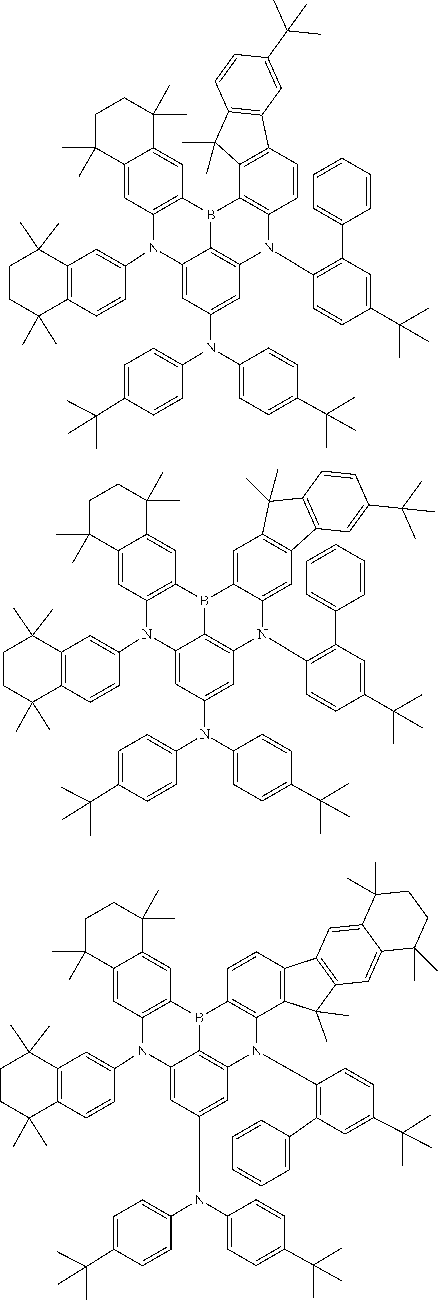

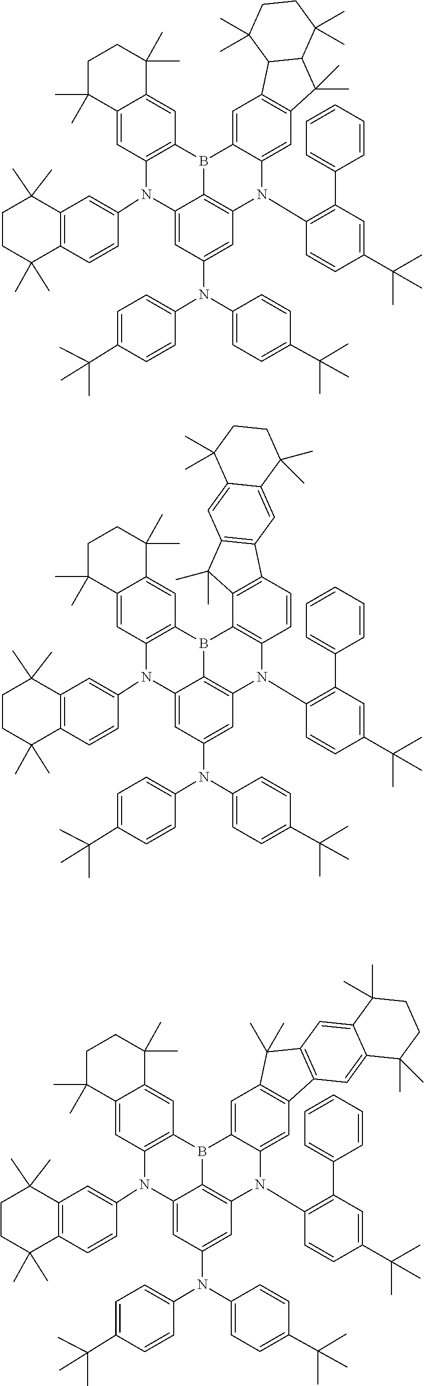

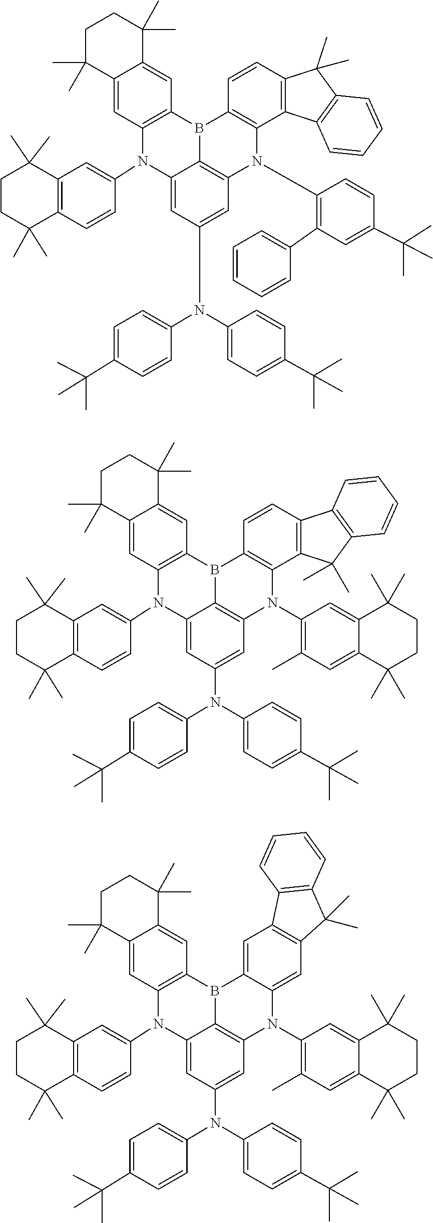

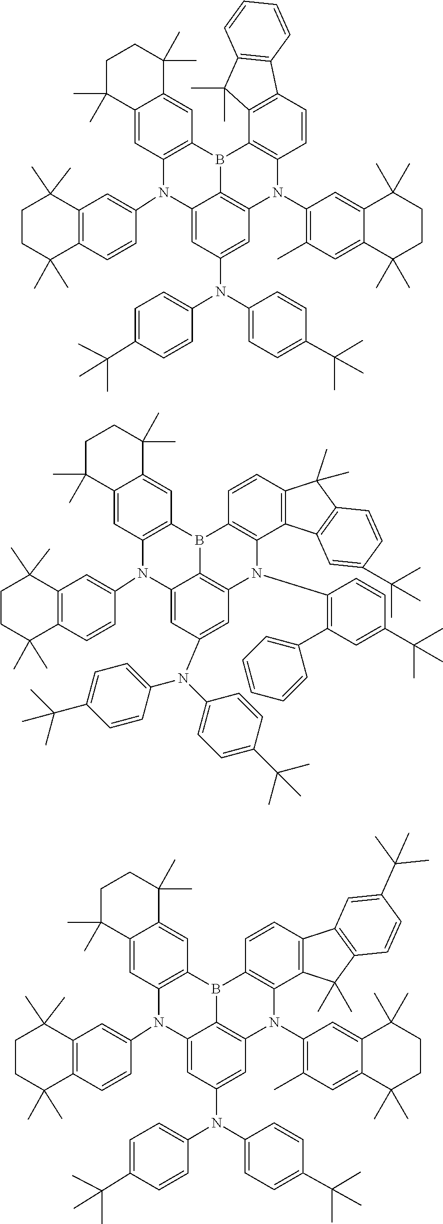

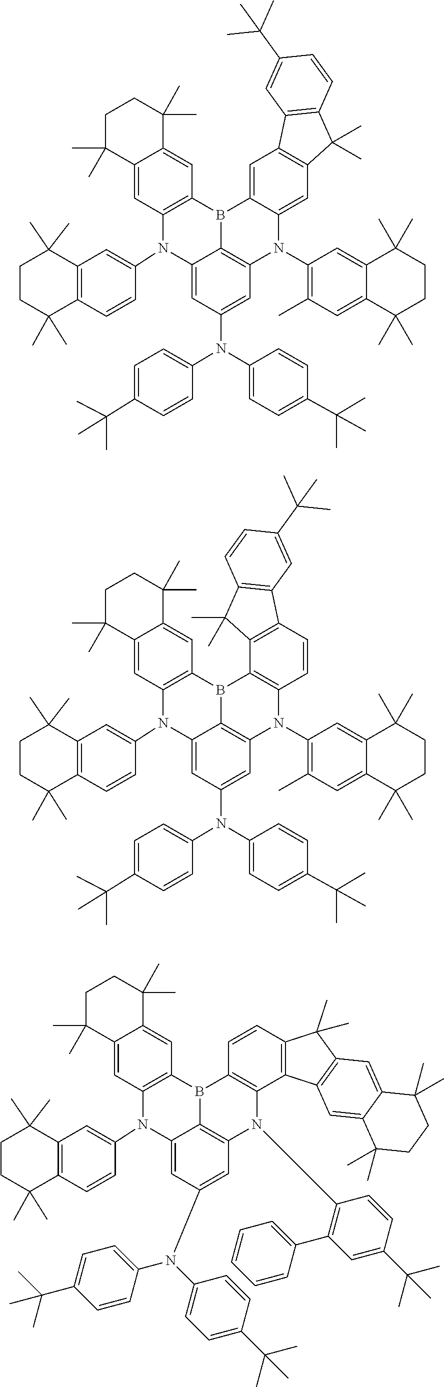

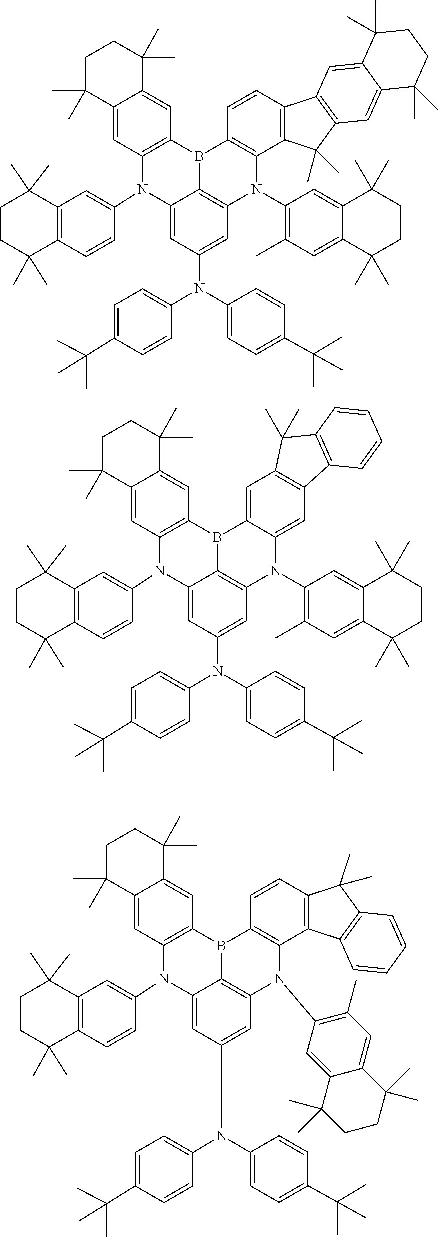

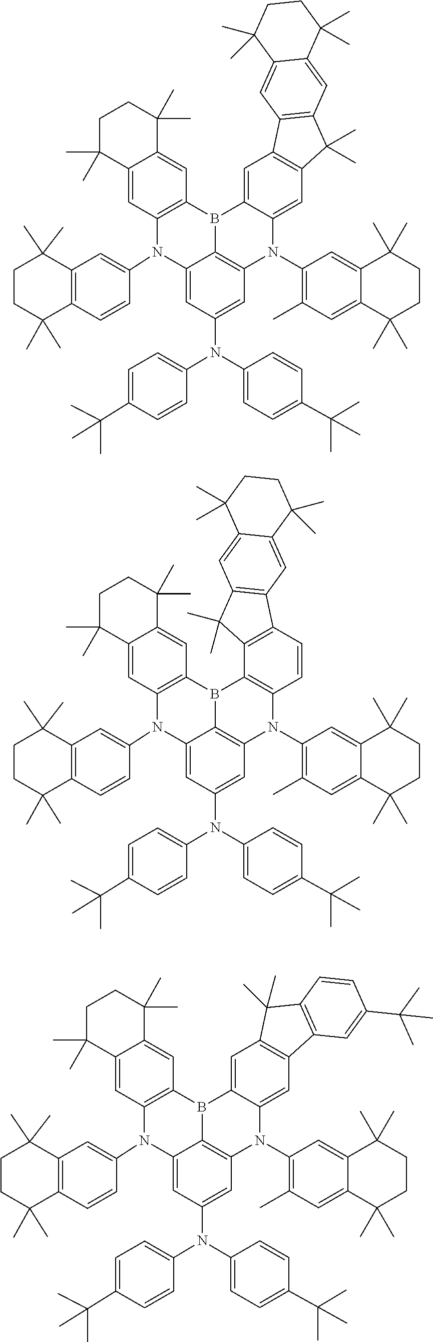

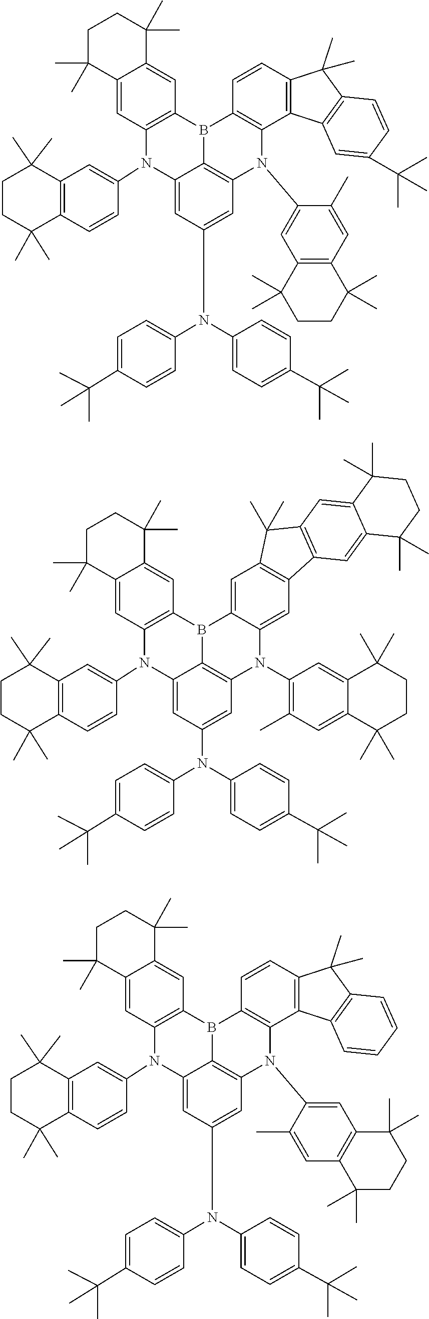

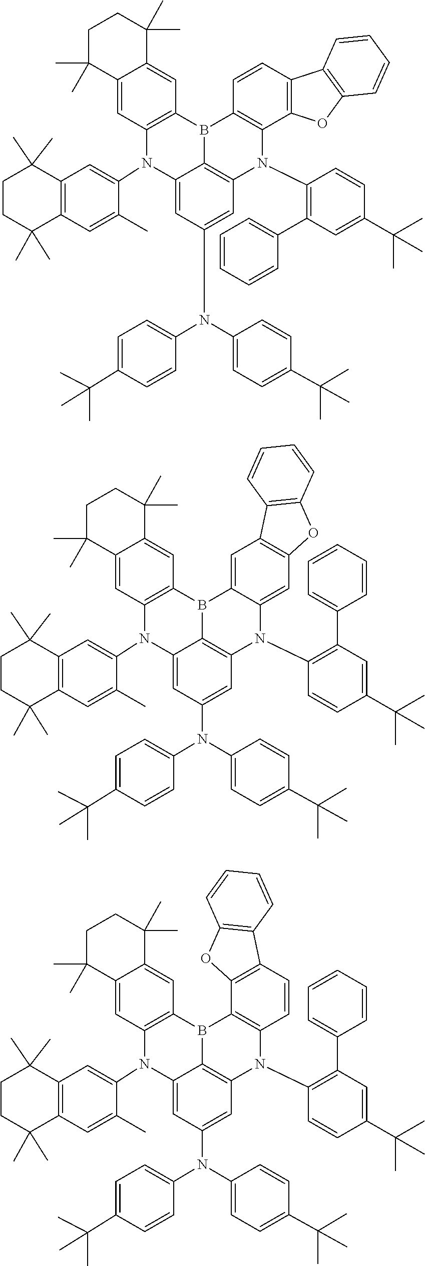

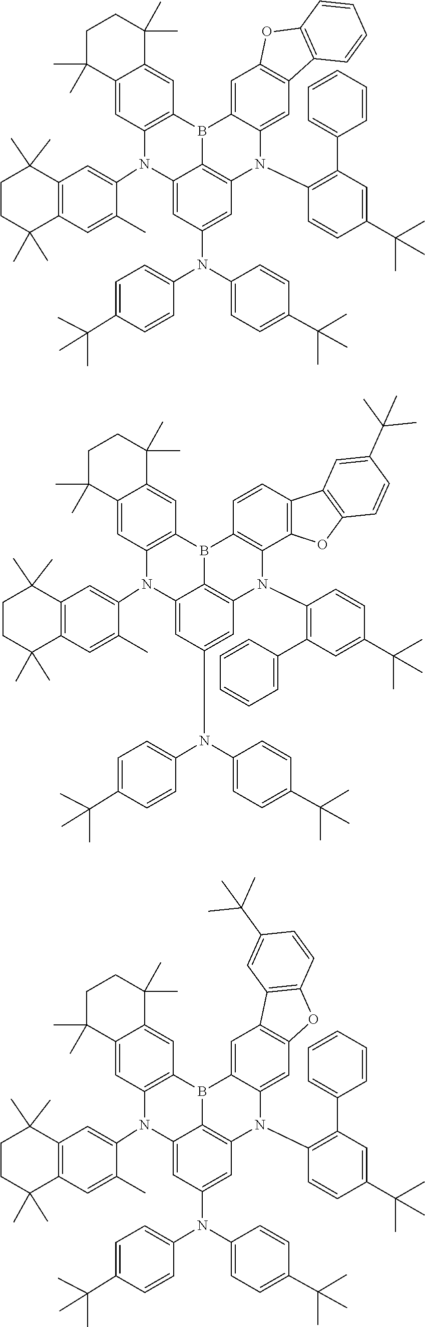

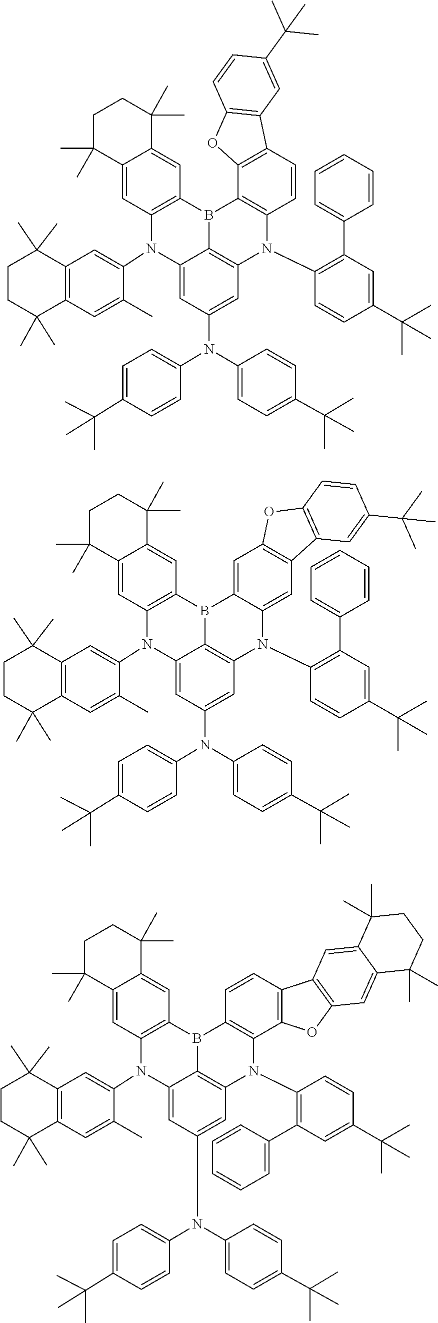

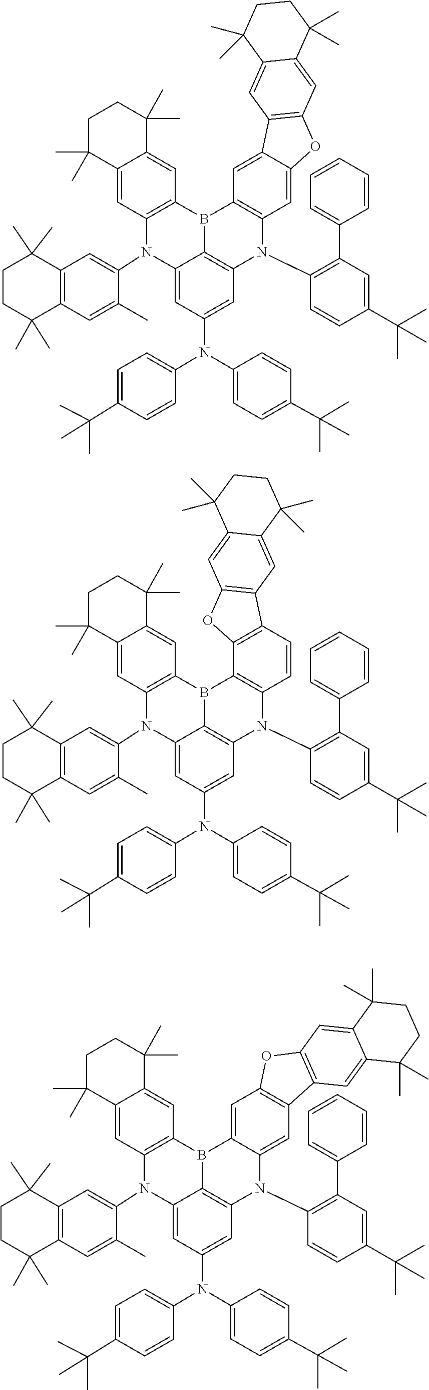

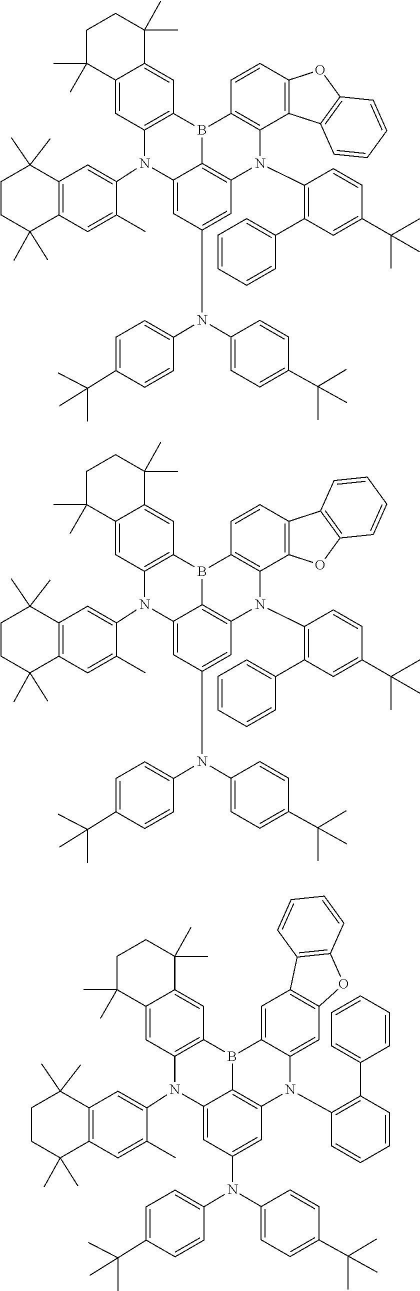

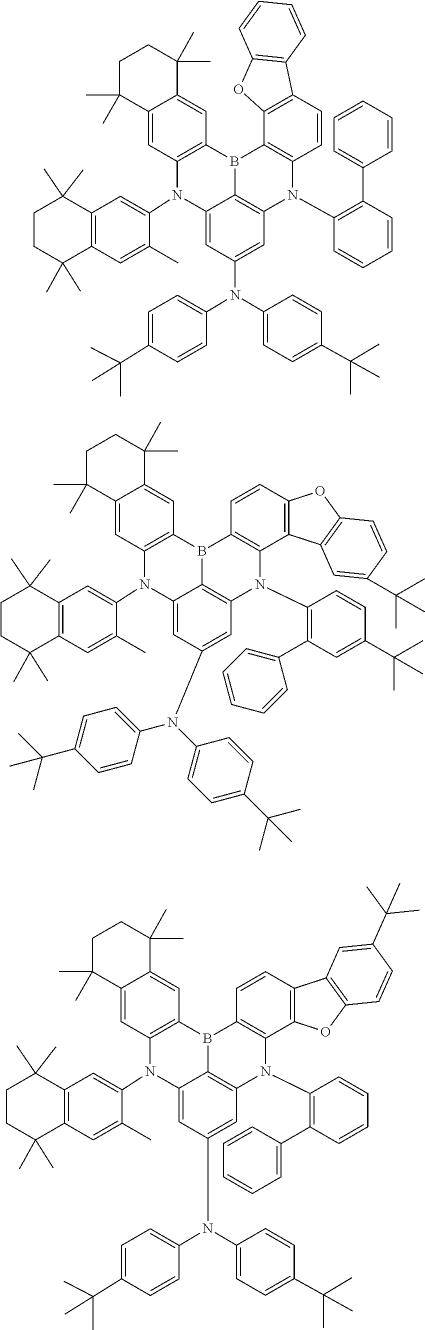

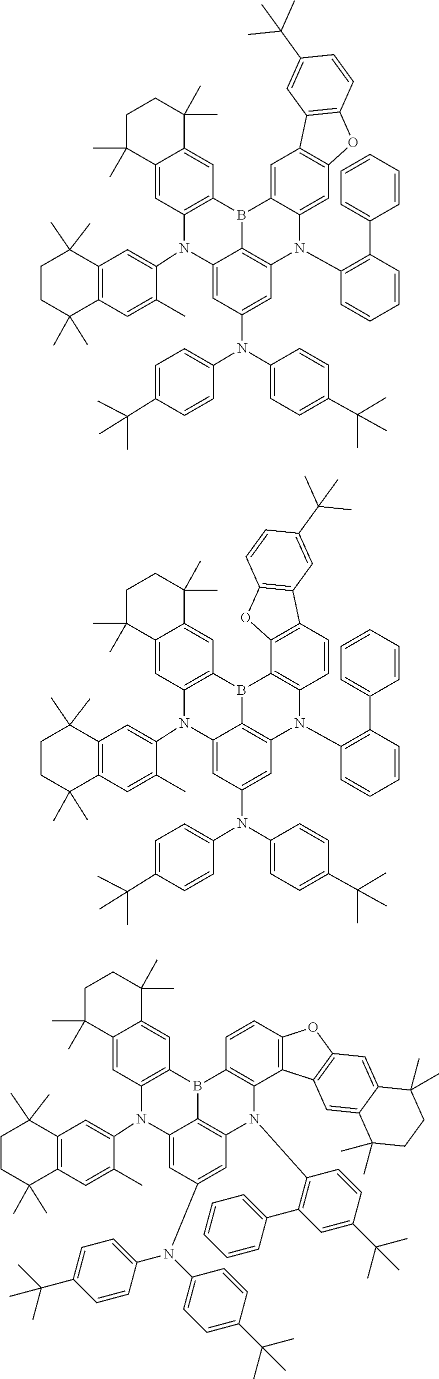

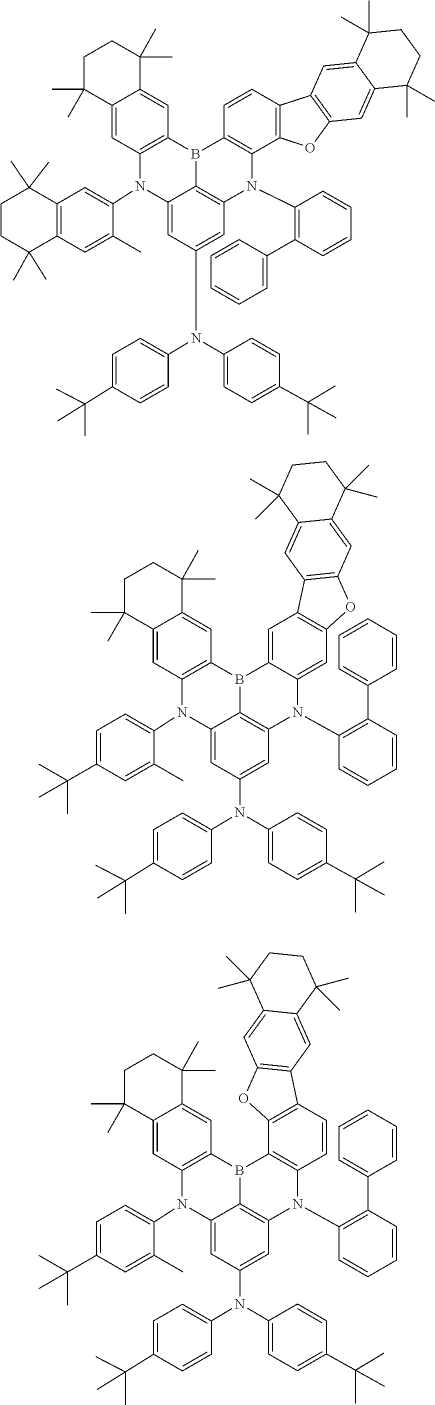

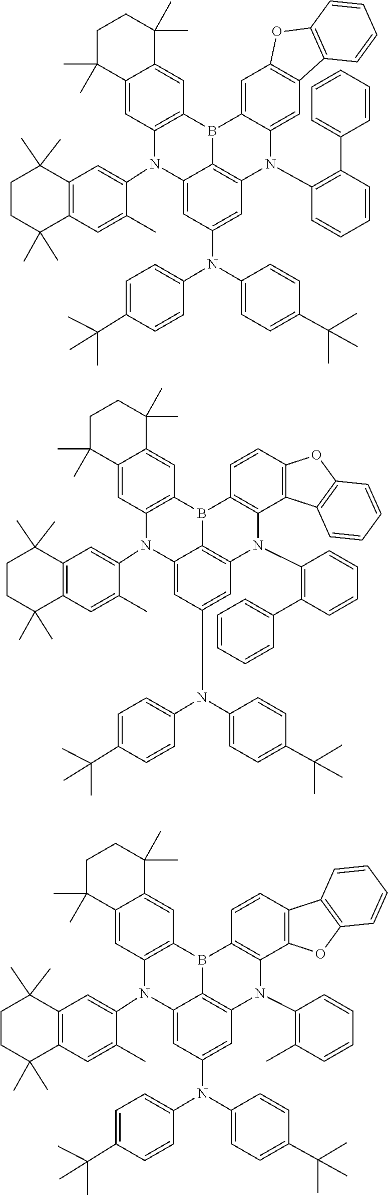

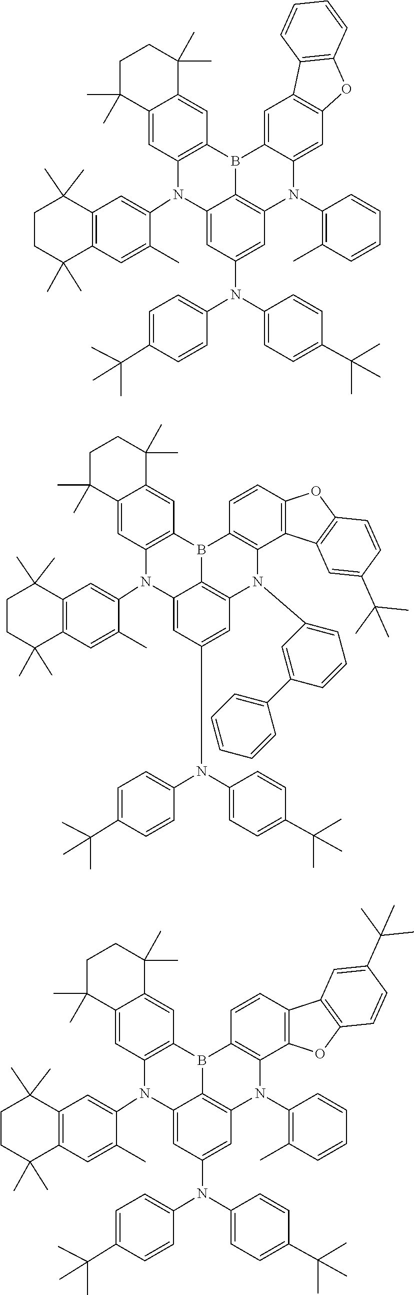

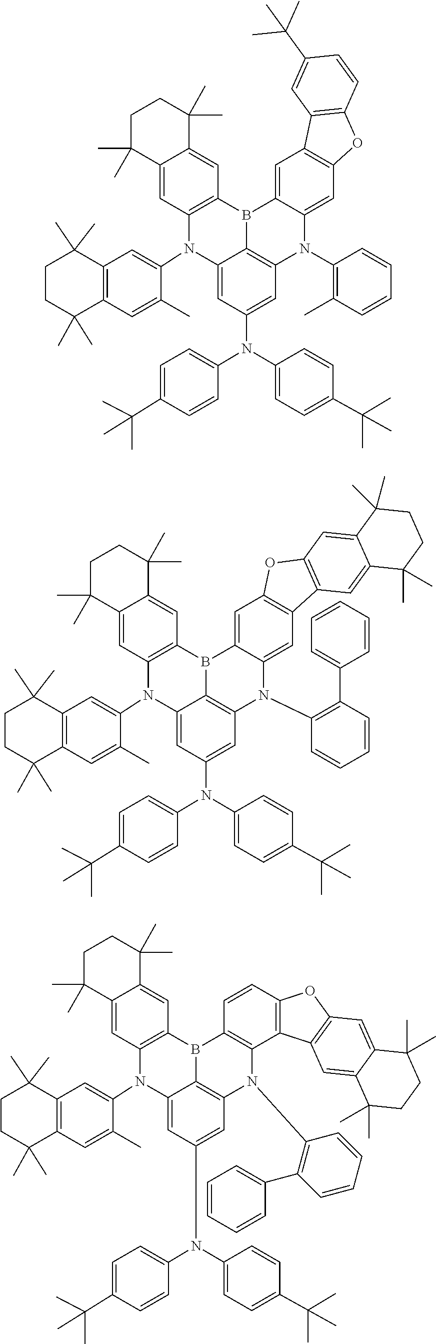

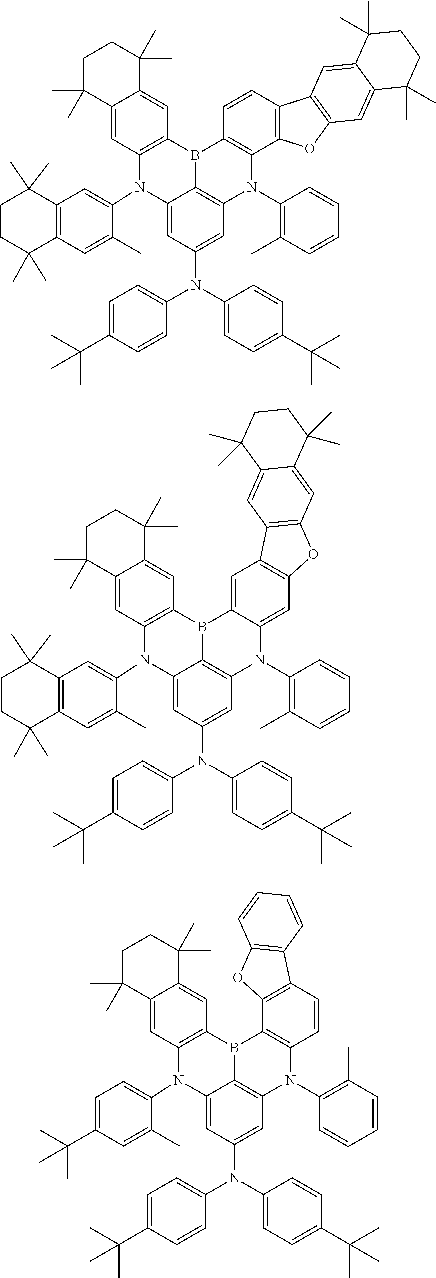

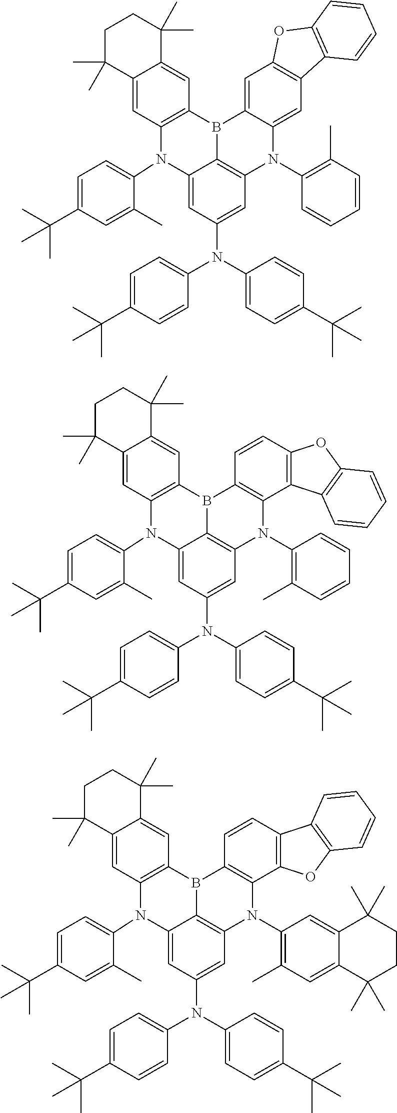

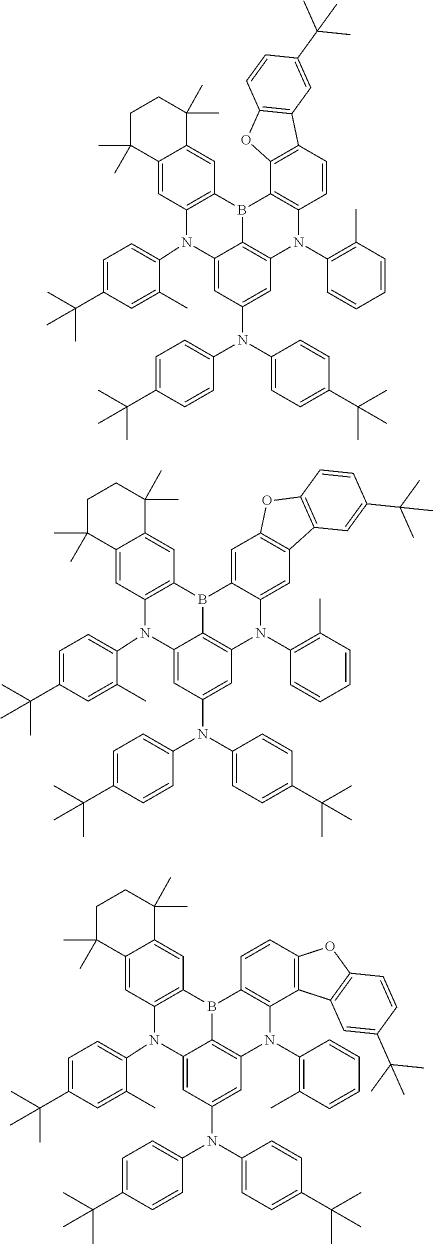

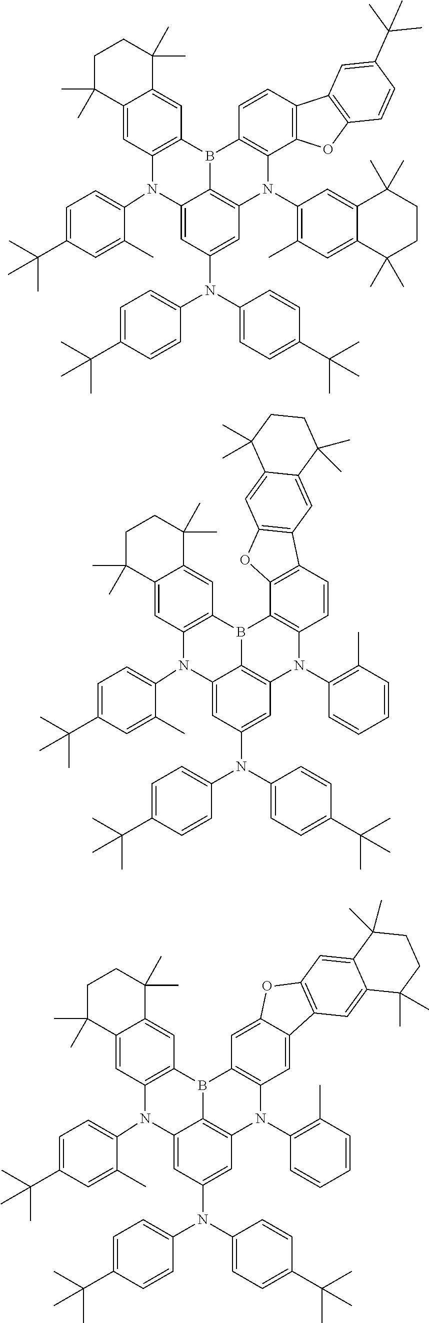

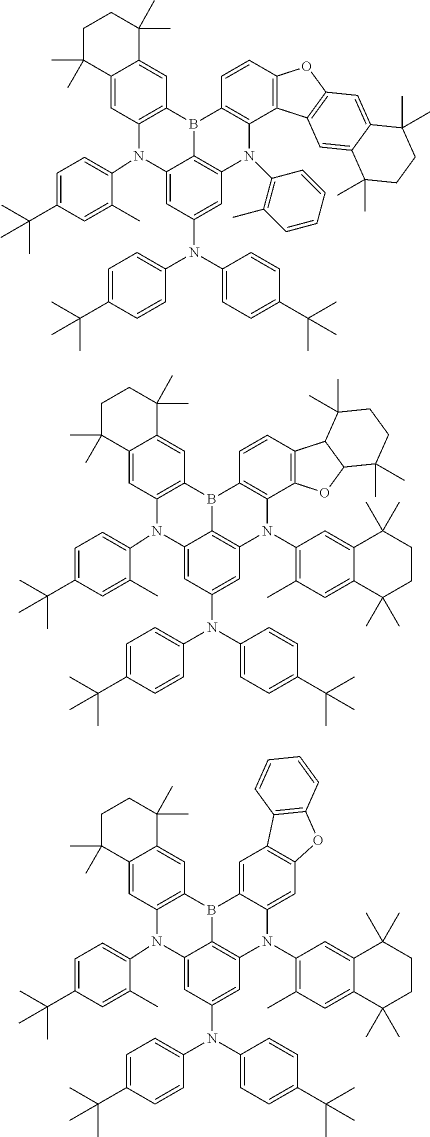

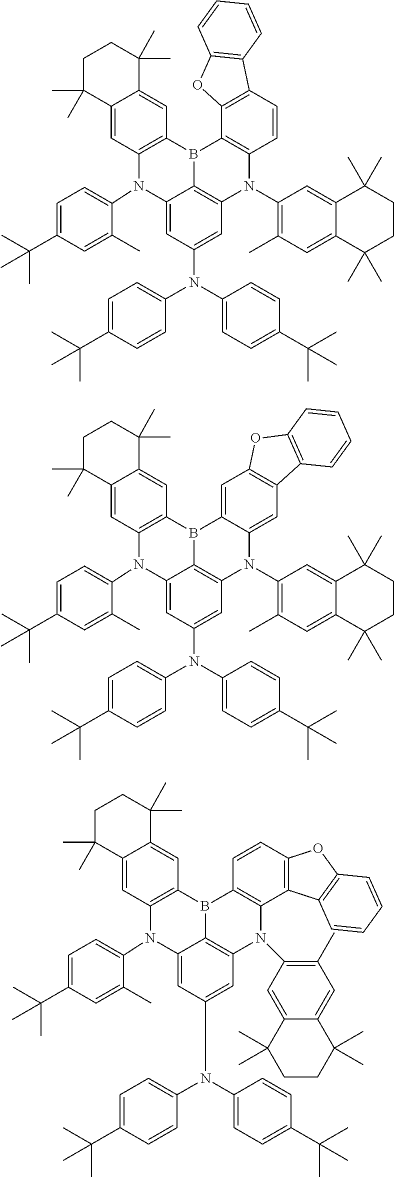

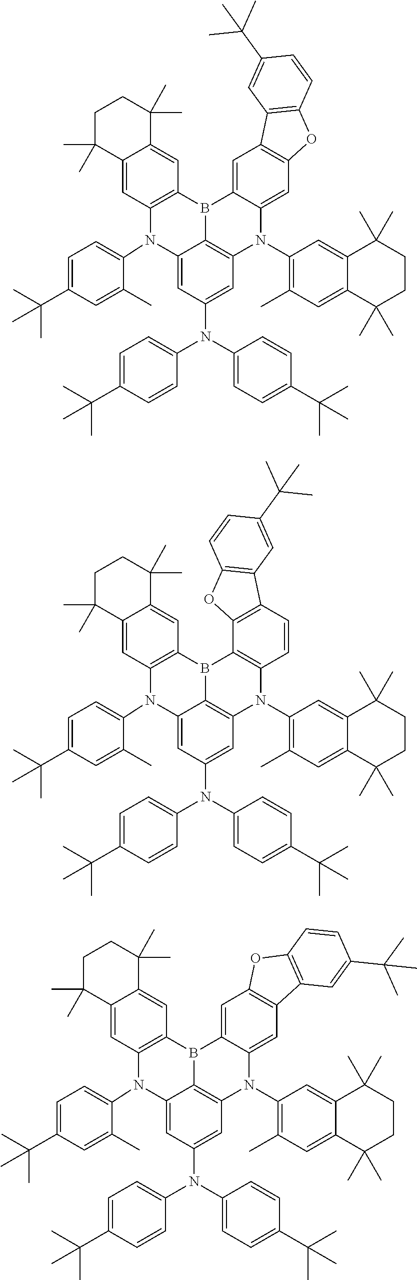

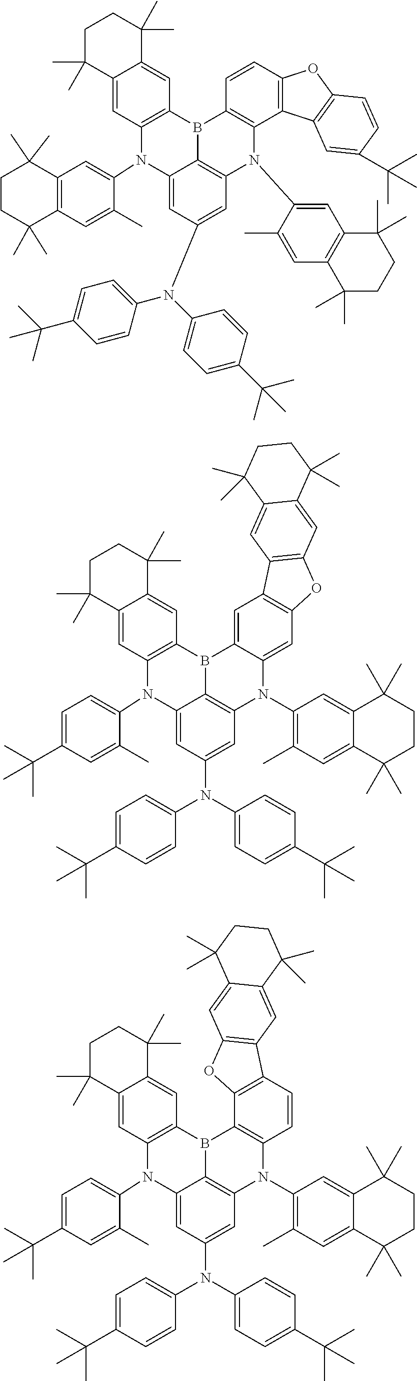

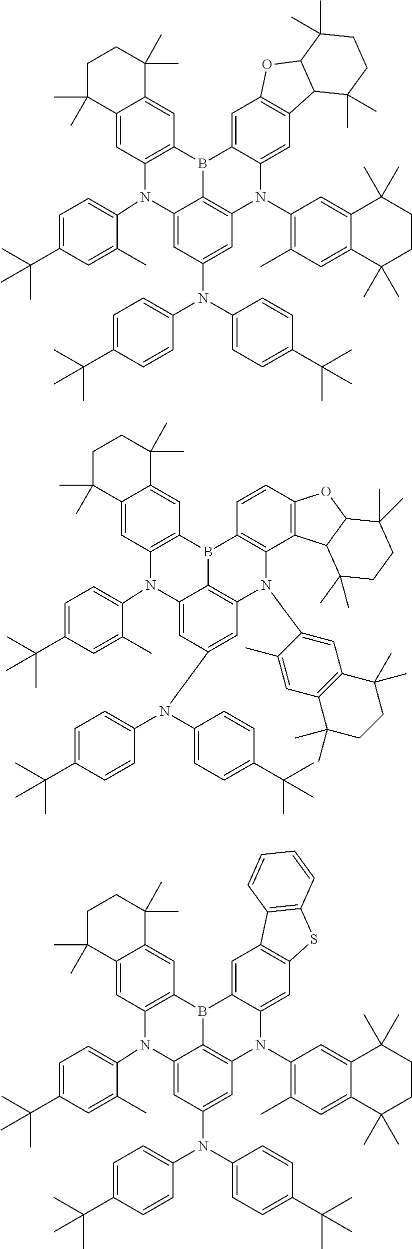

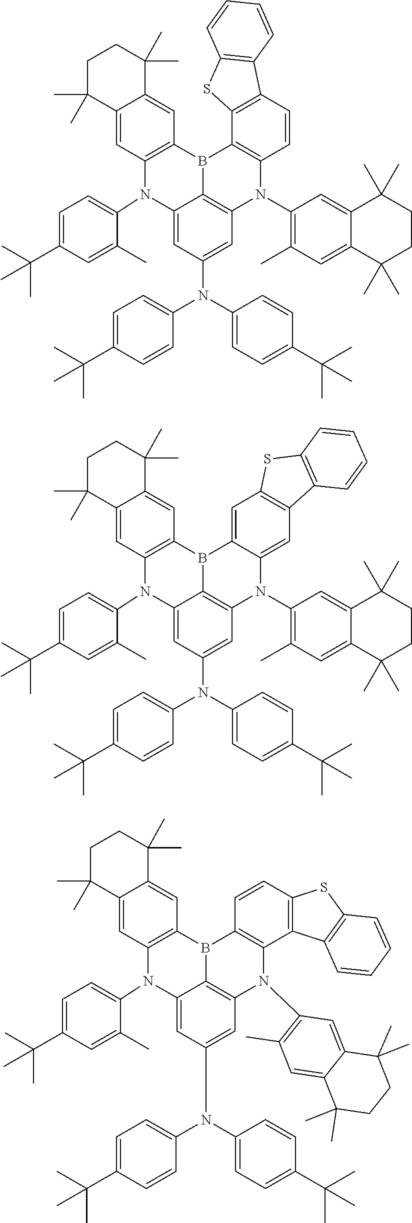

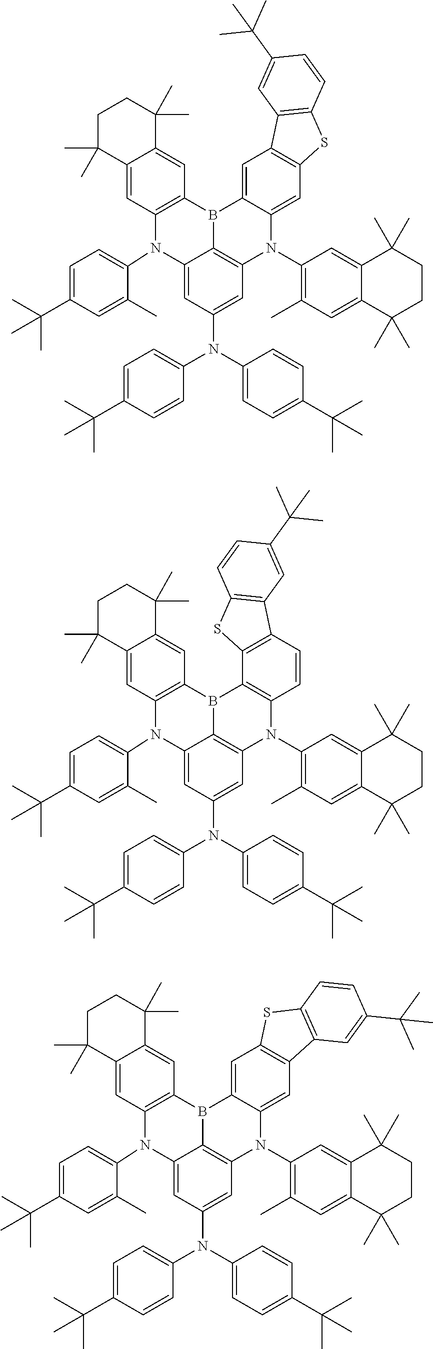

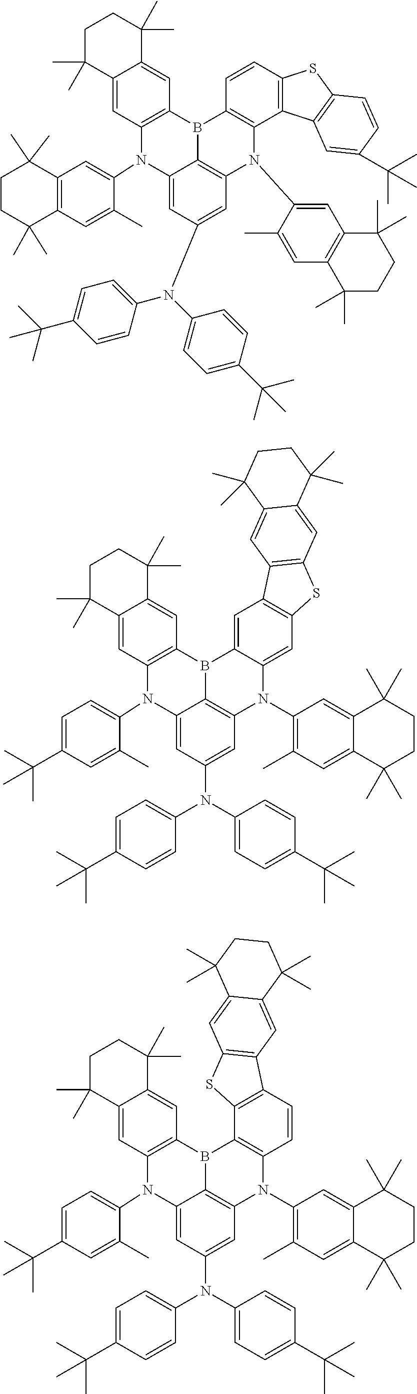

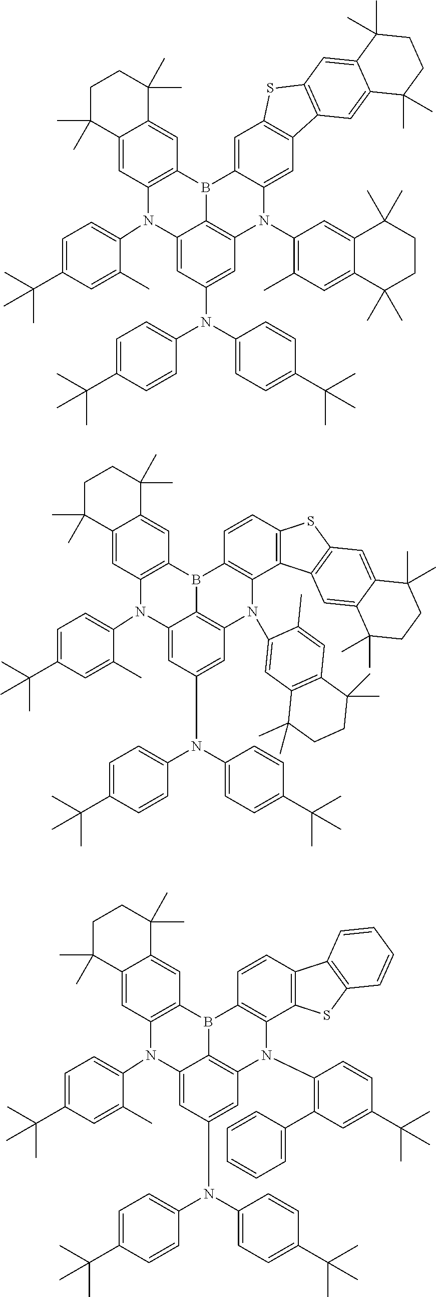

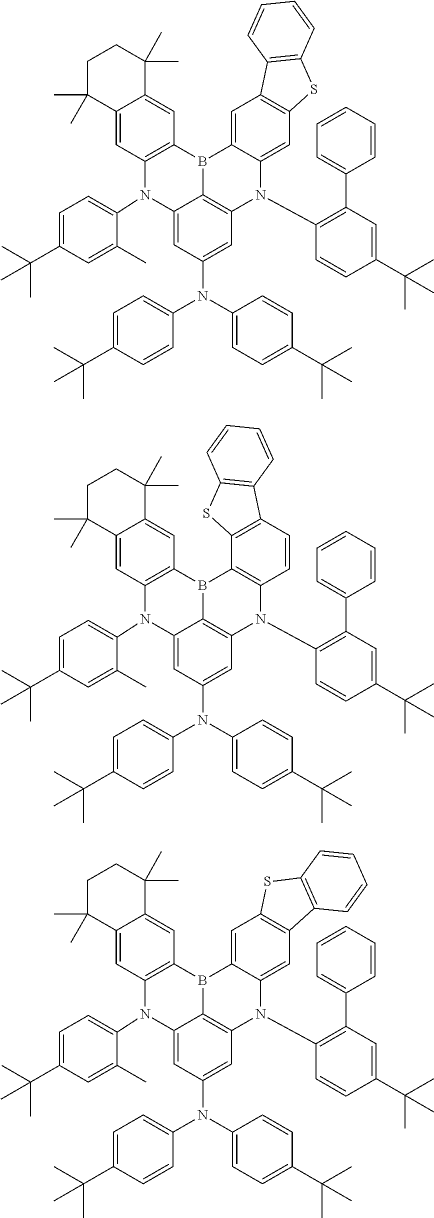

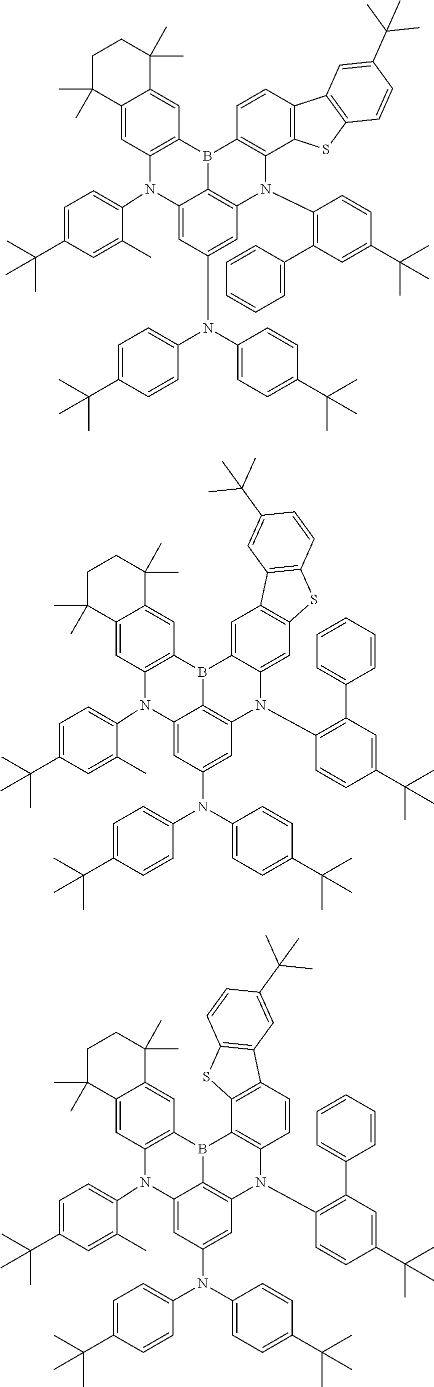

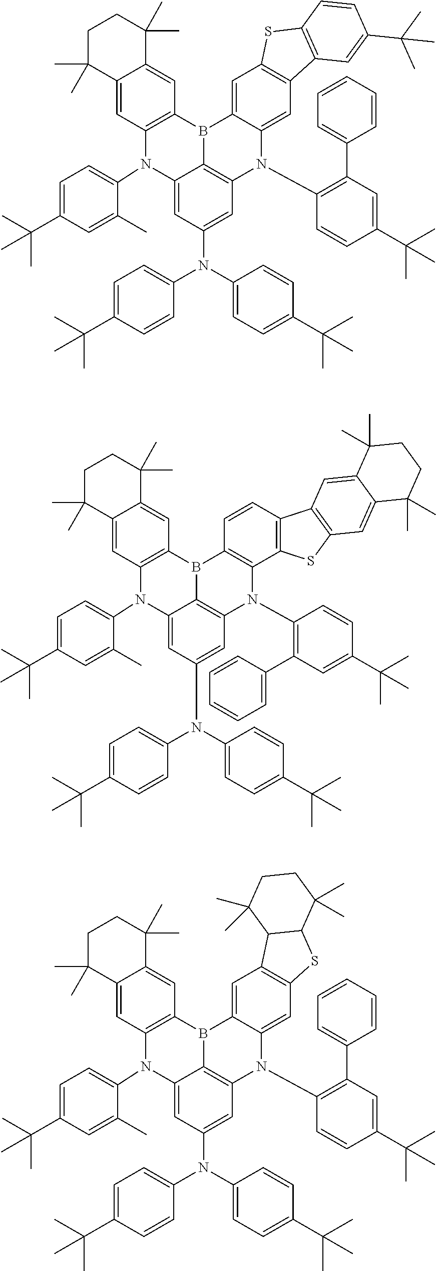

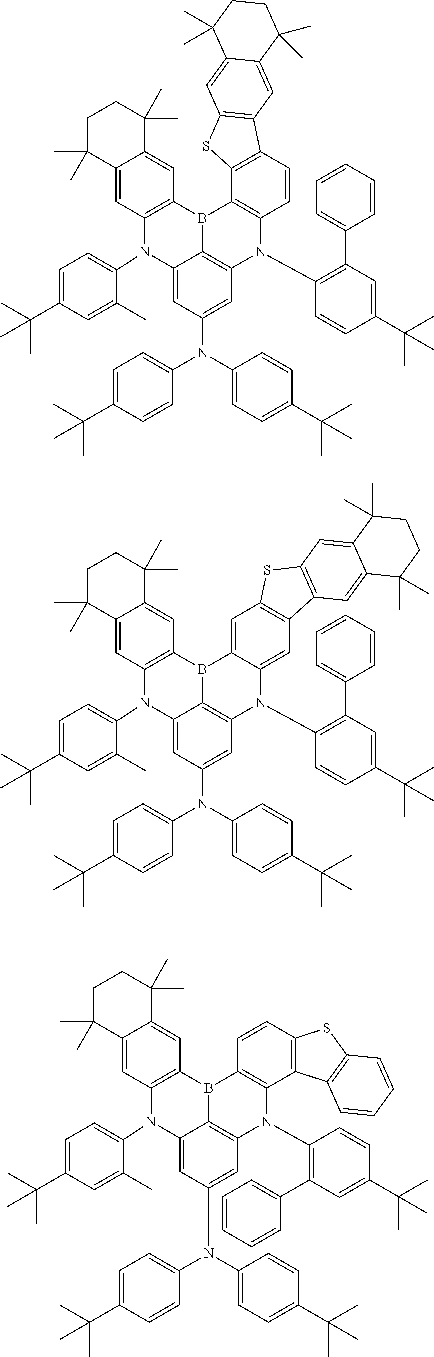

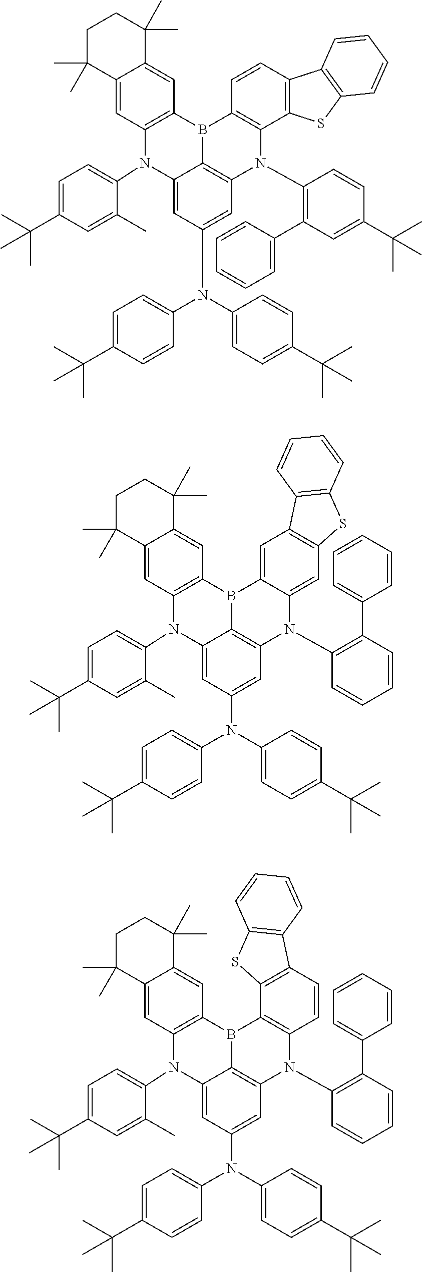

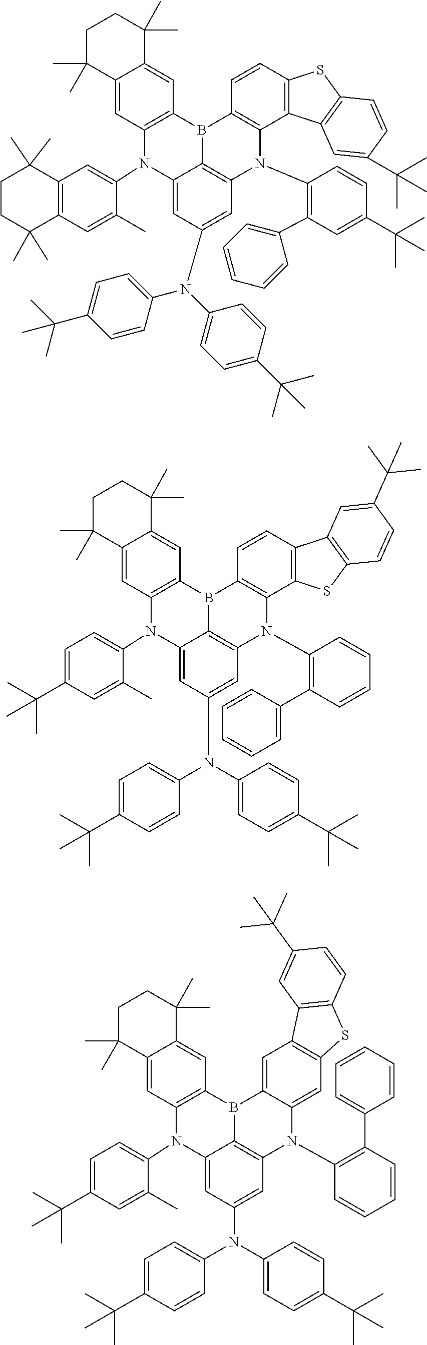

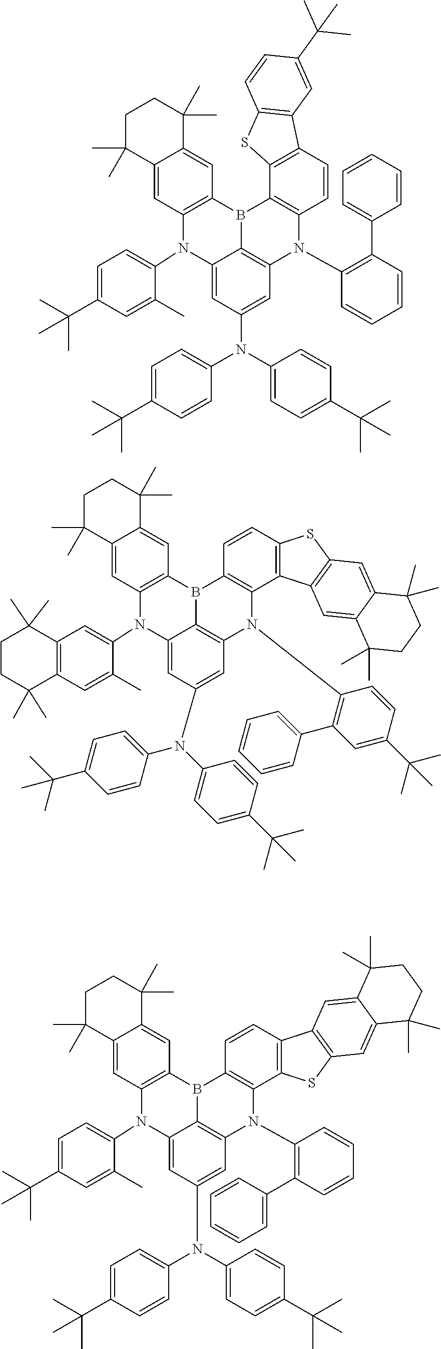

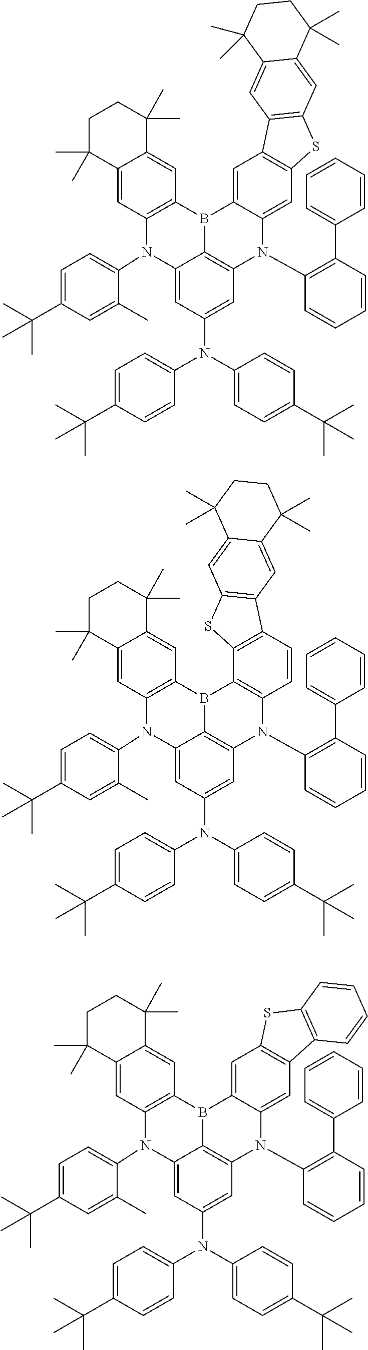

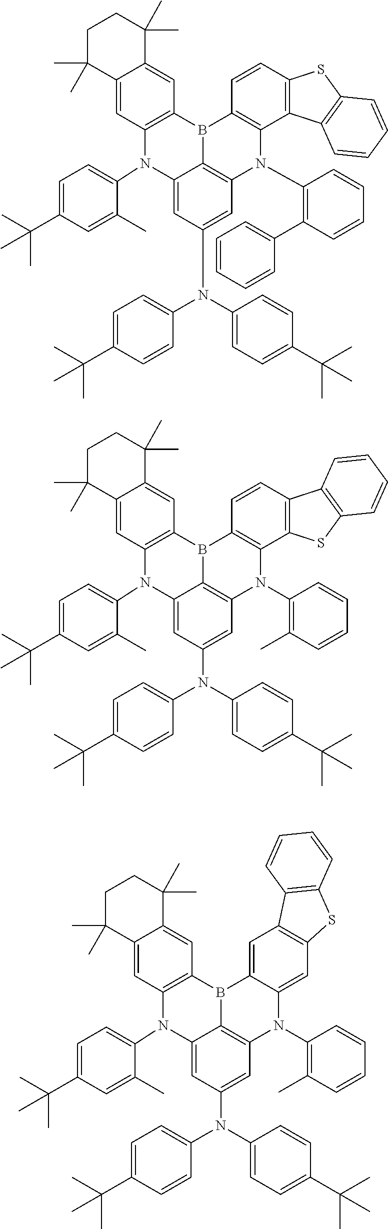 [SMILES: Cc1cc(C(C)(C)C)ccc1N1c2cc3c(cc2B2c4ccc5sc6ccccc6c5c4N(c4ccccc4-c4ccccc4)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4ccc5c(sc6ccccc65)c4N(c4ccccc4C)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4cc5c(cc4N(c4ccccc4C)c4cc(N(c6ccc(C(C)(C)C)cc6)c6ccc(C(C)(C)C)cc6)cc1c42)sc1ccccc15)C(C)(C)CCC3(C)C]

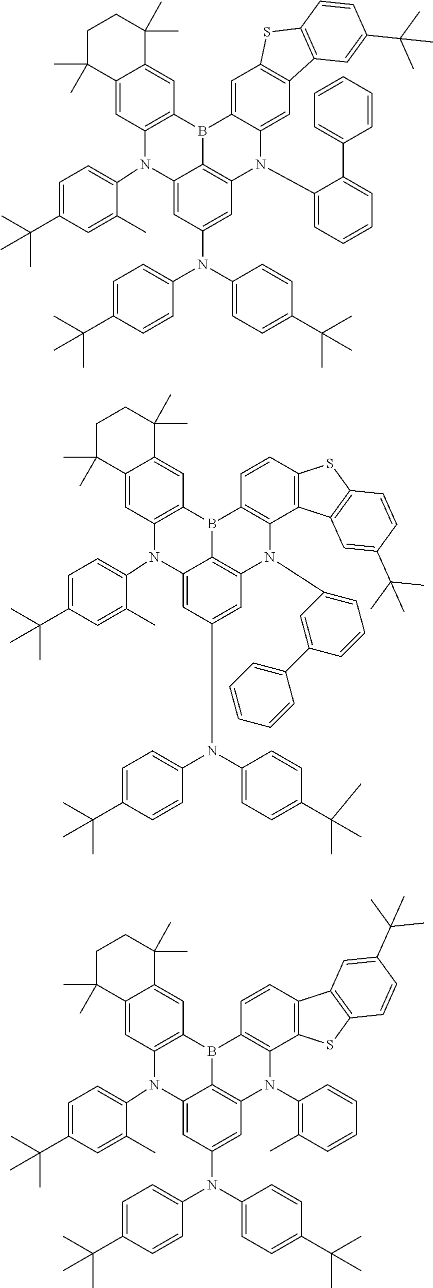

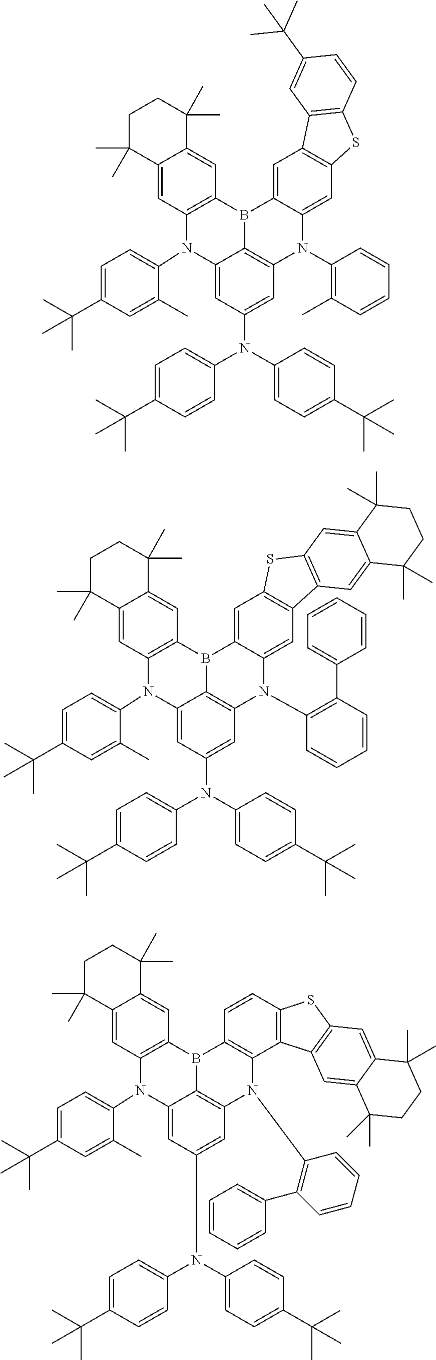

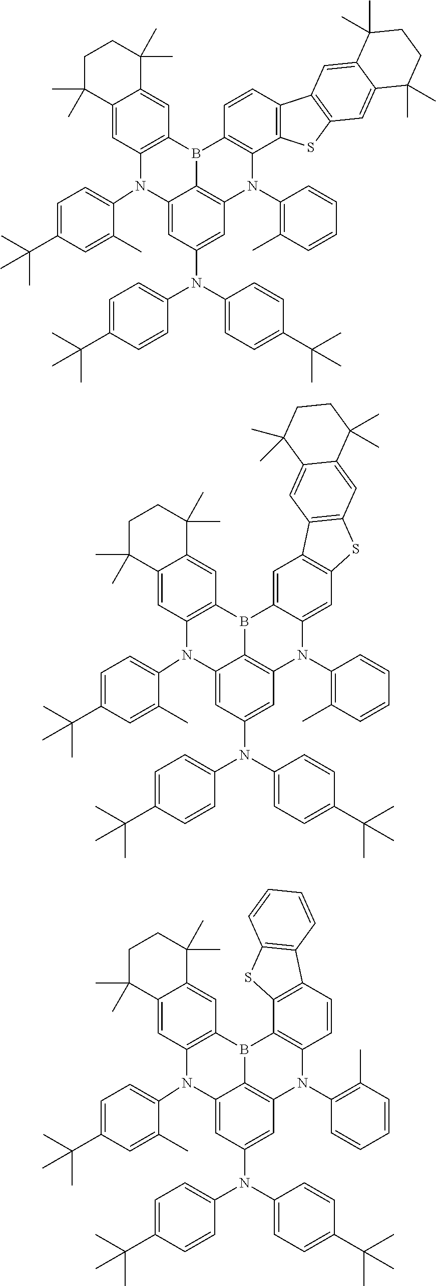

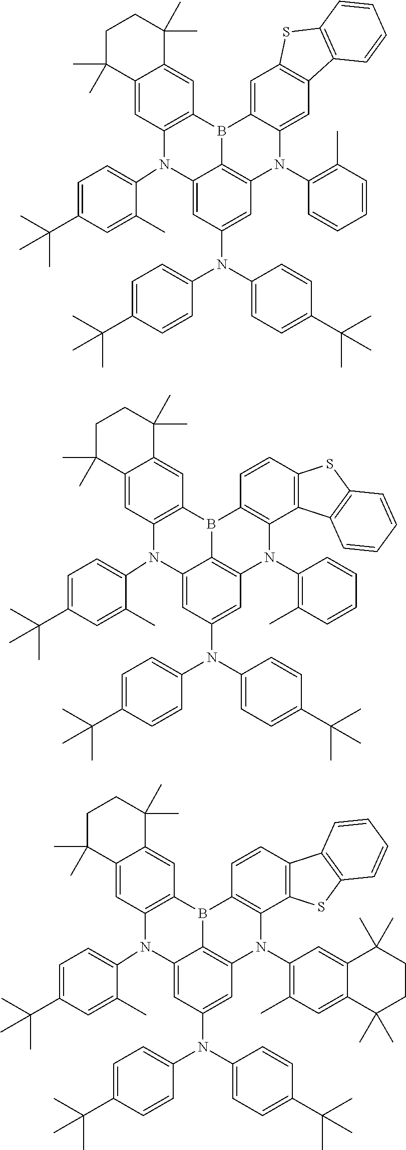

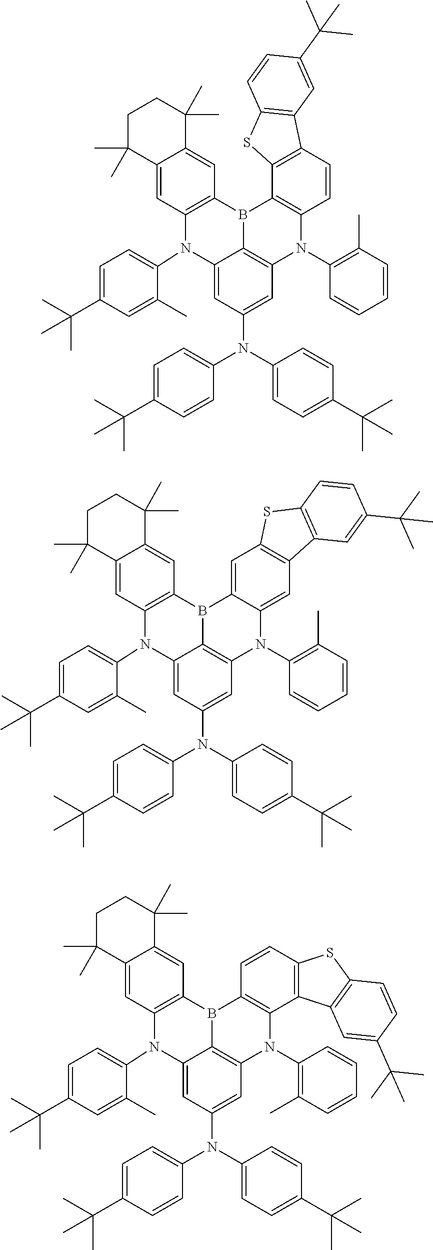

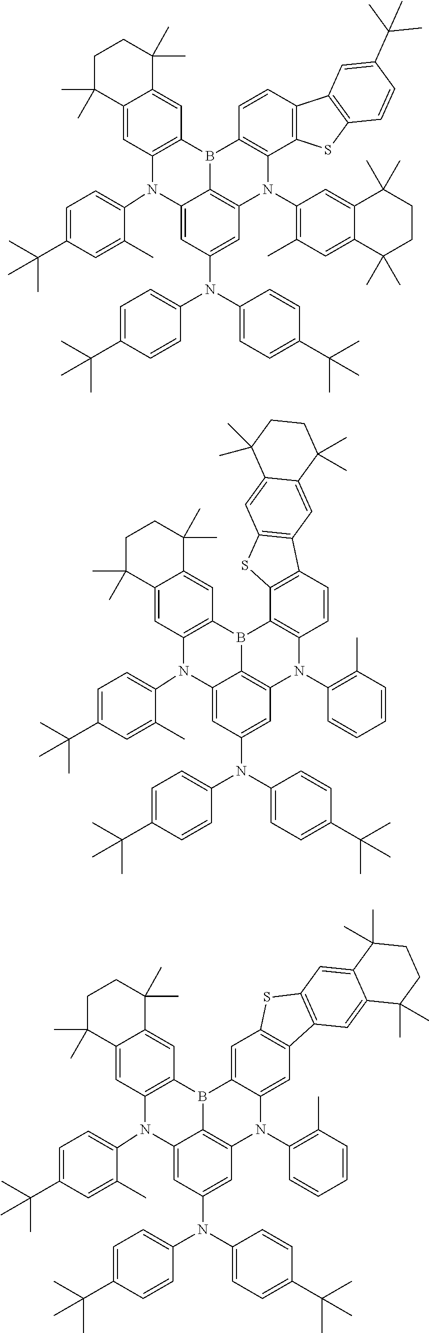

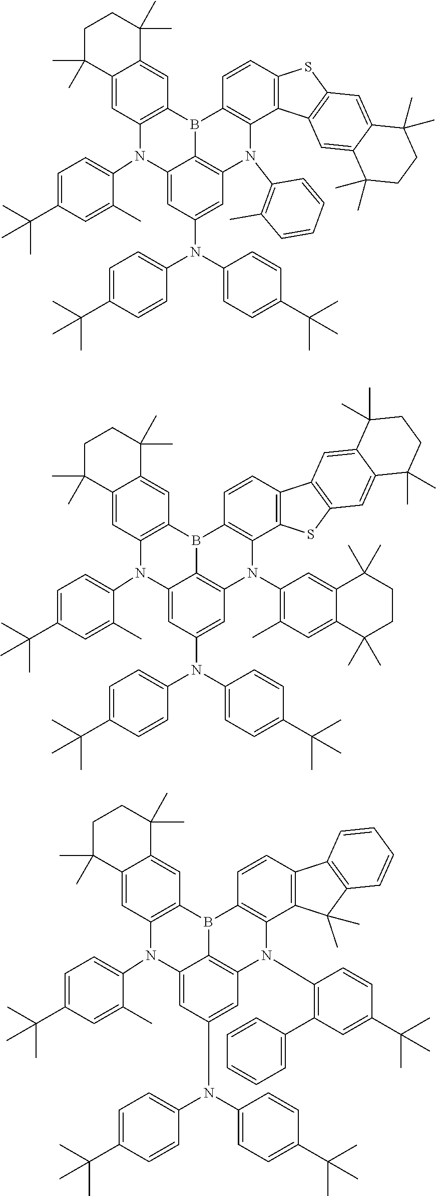

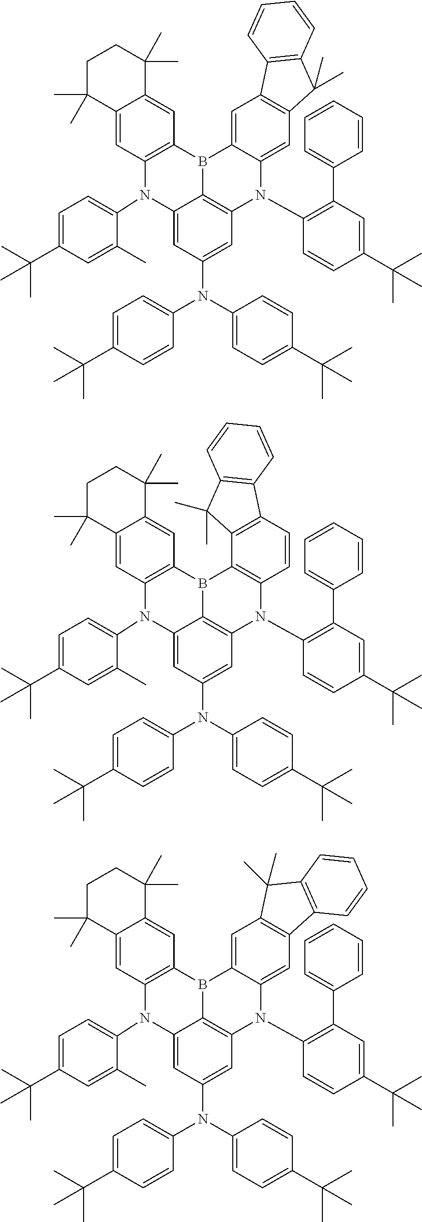

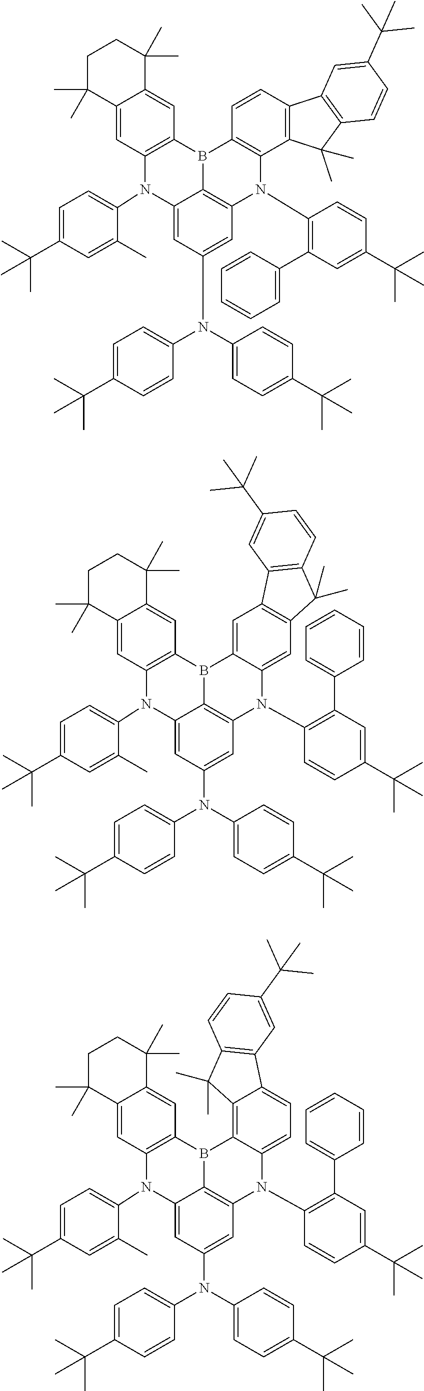

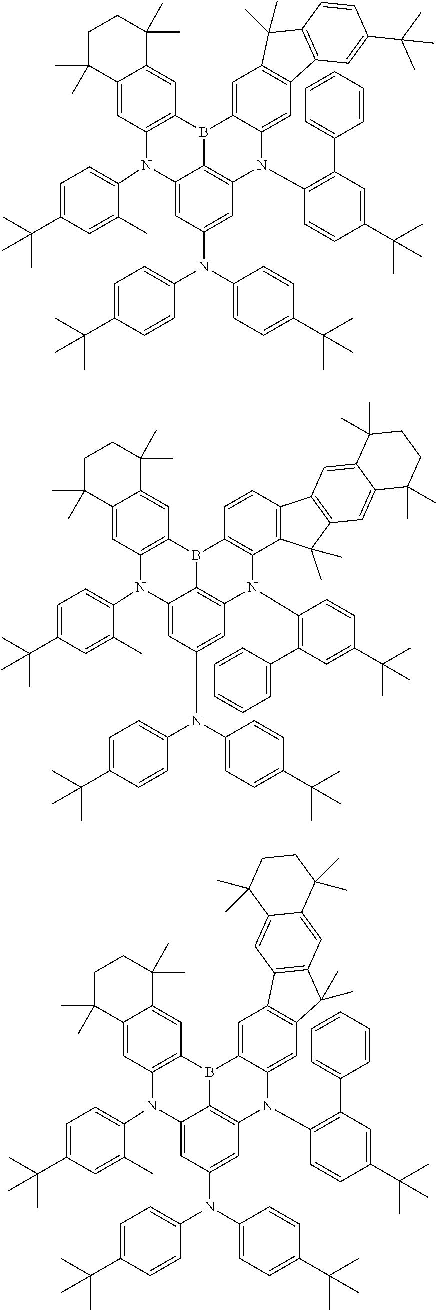

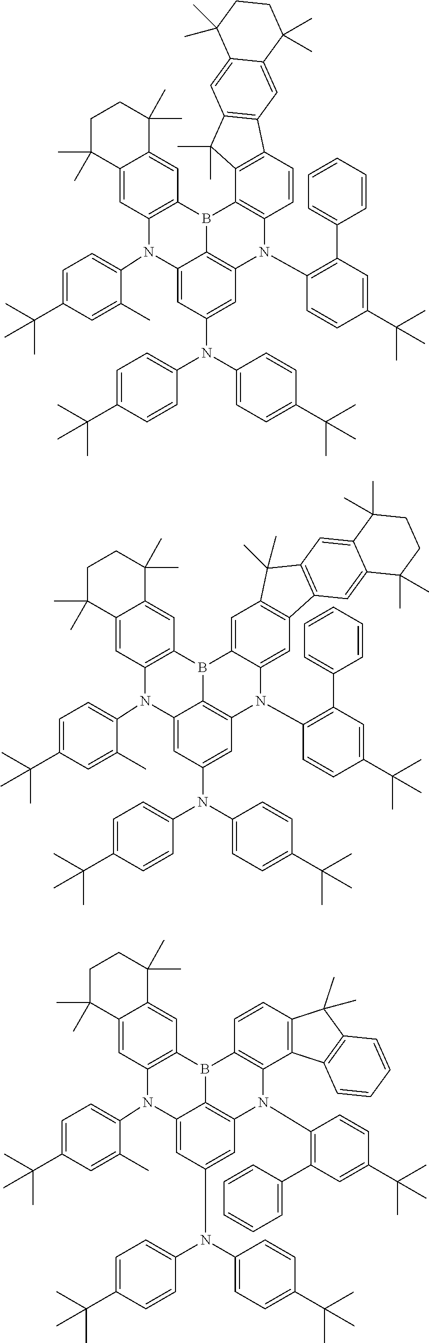

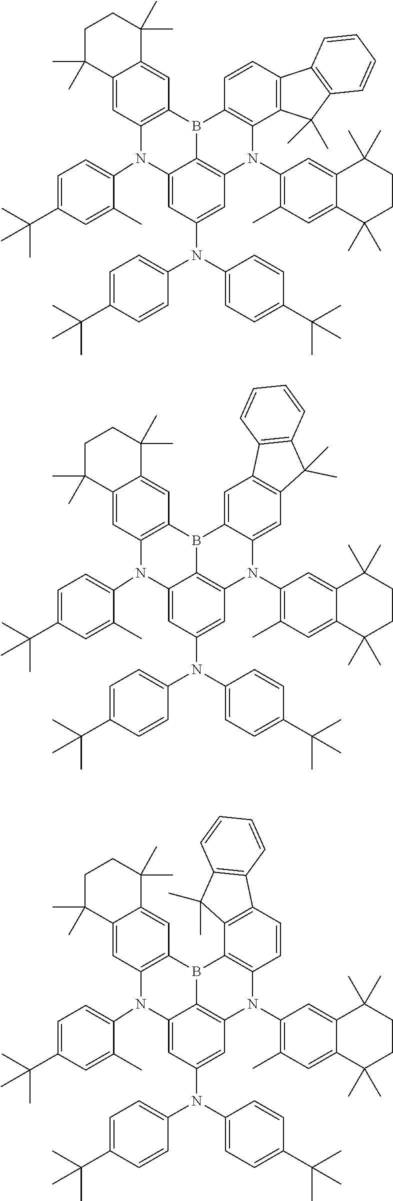

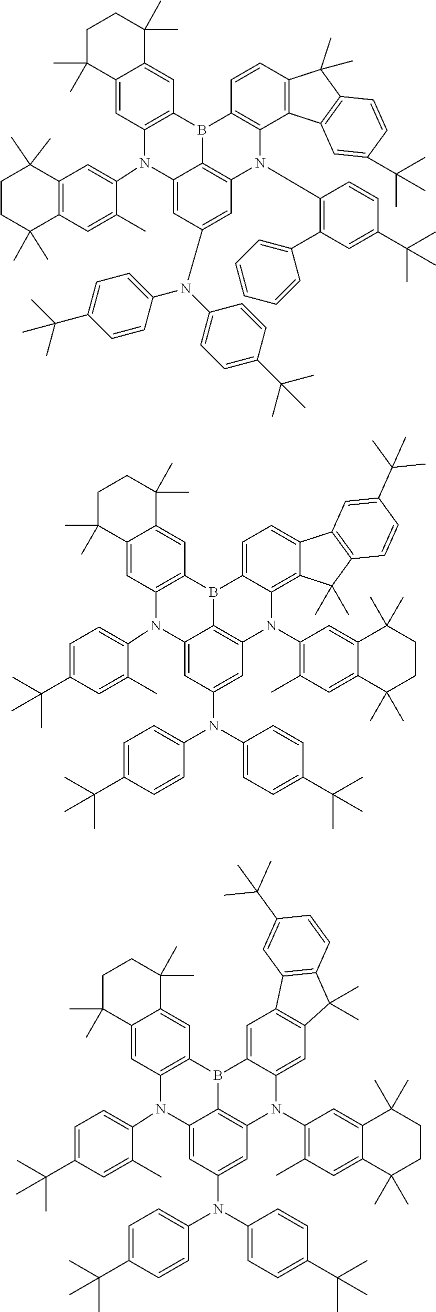

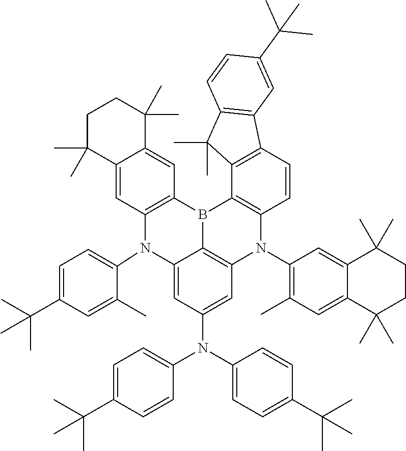 [SMILES: Cc1cc(C(C)(C)C)ccc1N1c2cc3c(cc2B2c4c1cc(N(c1ccc(C(C)(C)C)cc1)c1ccc(C(C)(C)C)cc1)cc4N(c1cc4c(cc1C)C(C)(C)CCC4(C)C)c1ccc4c(c12)C(C)(C)c1ccc(C(C)(C)C)cc1-4)C(C)(C)CCC3(C)C]

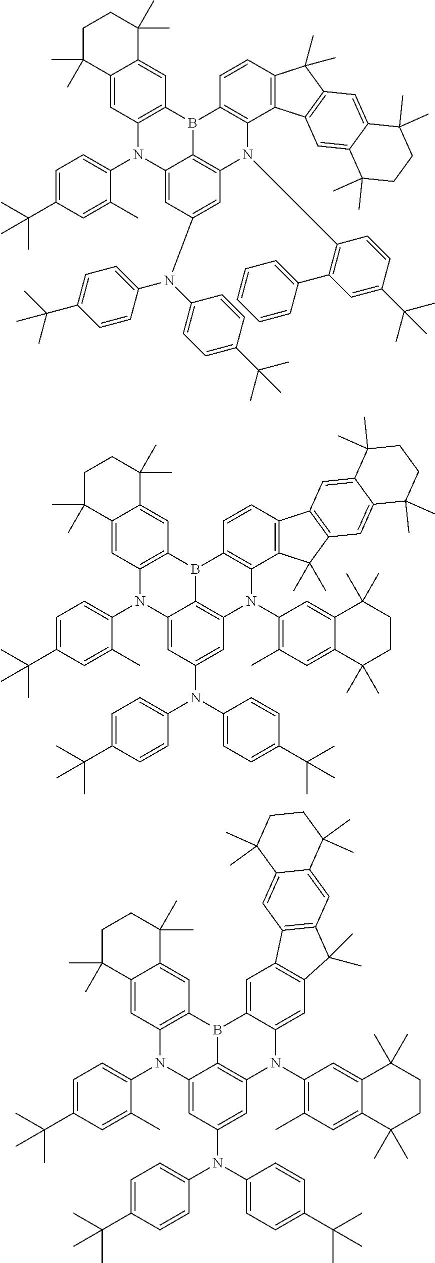

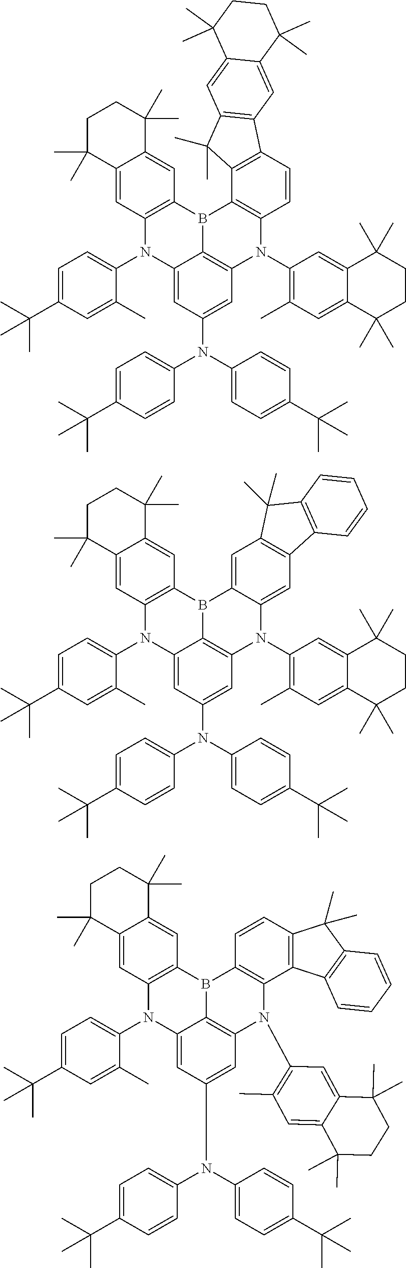

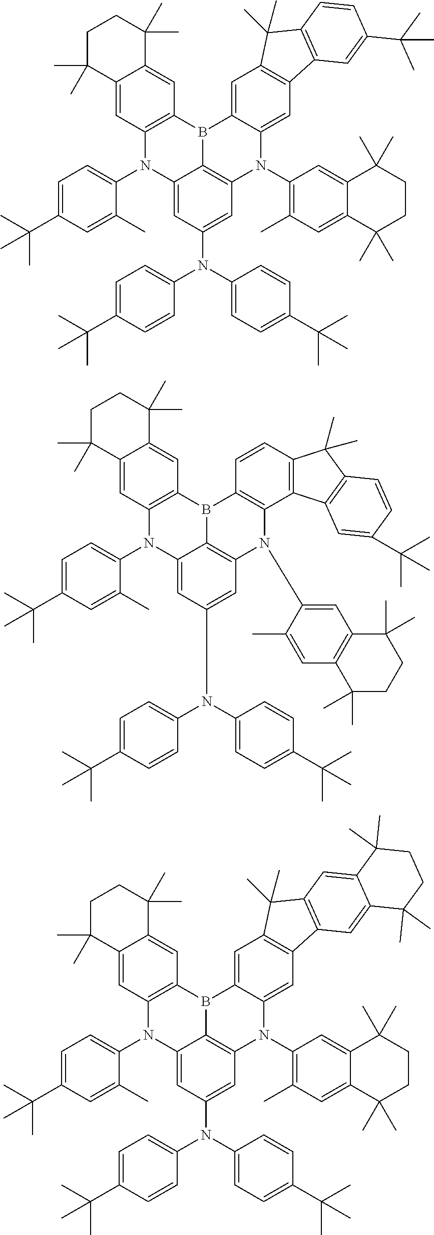

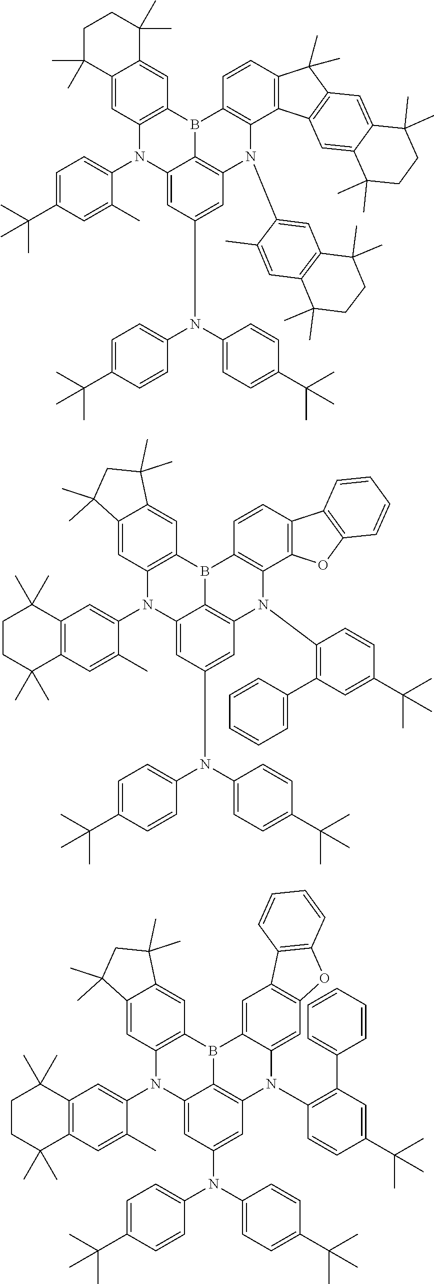

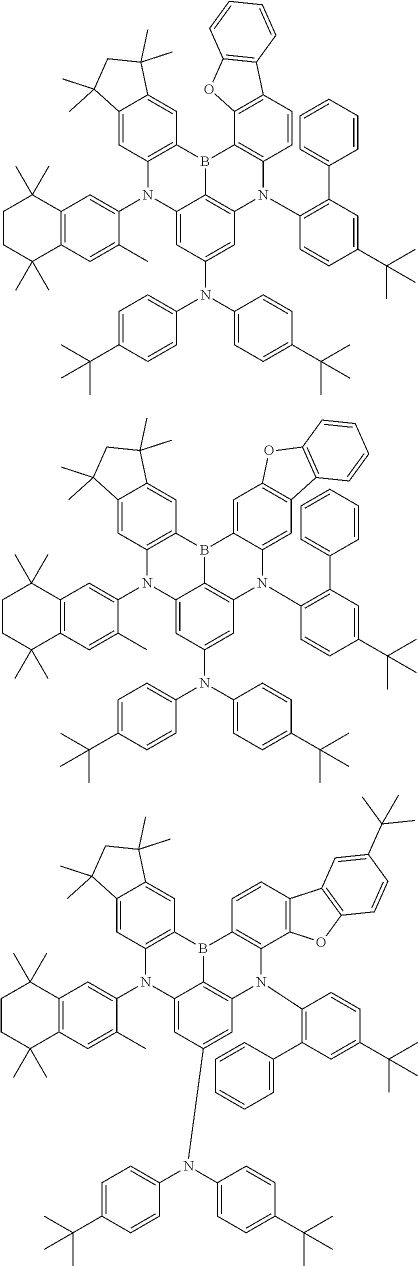

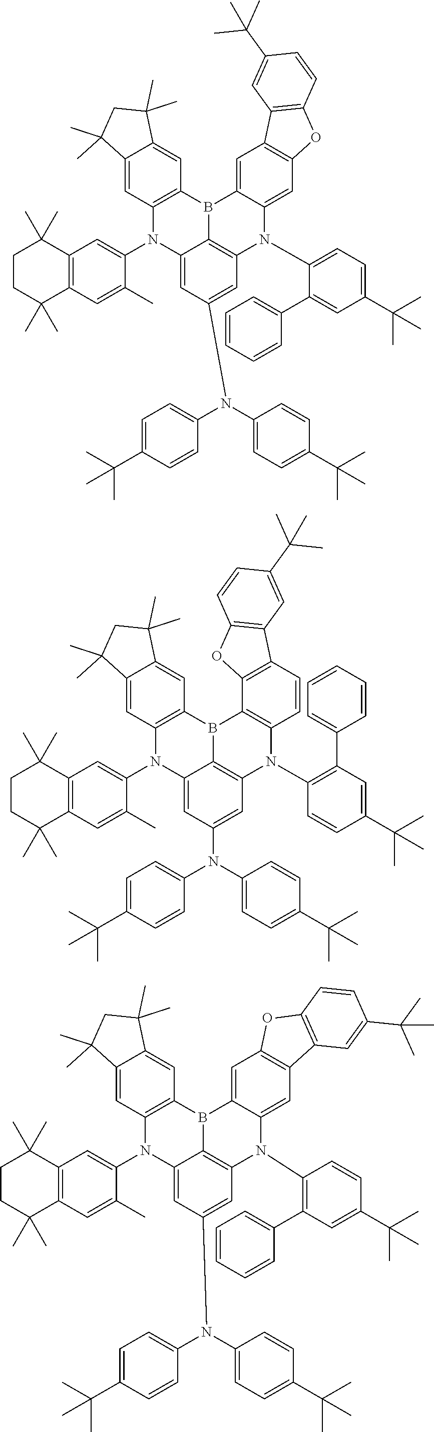

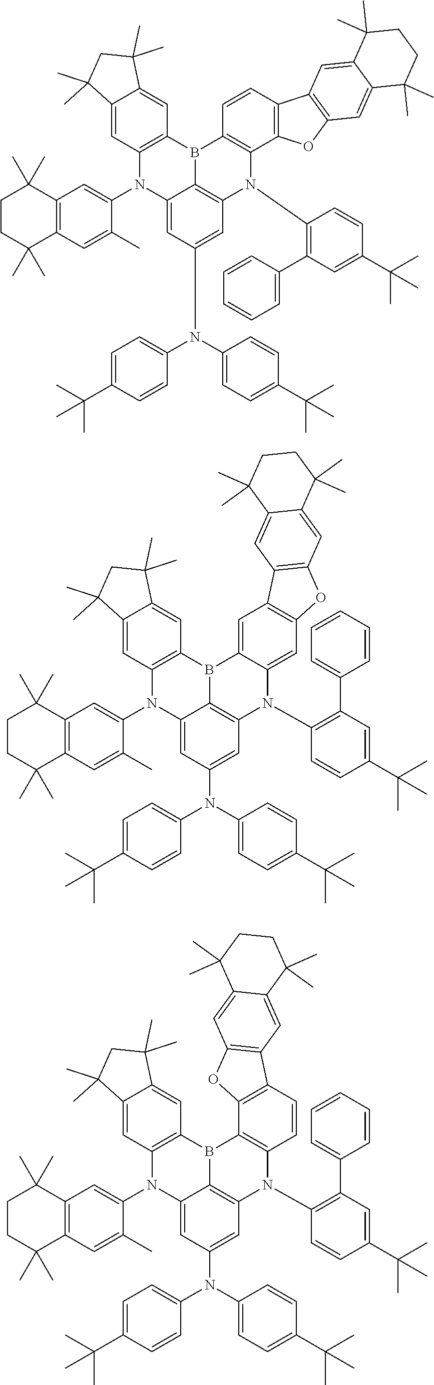

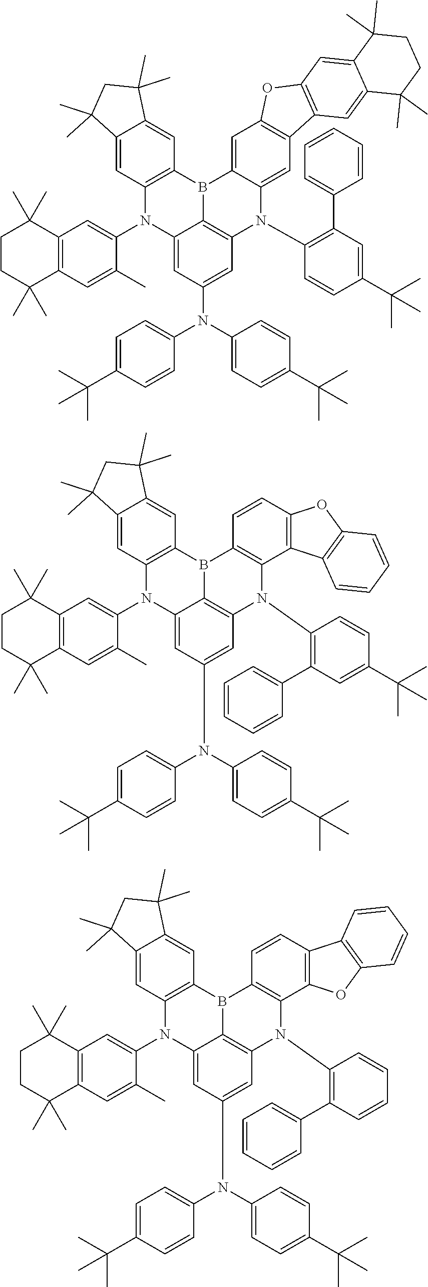

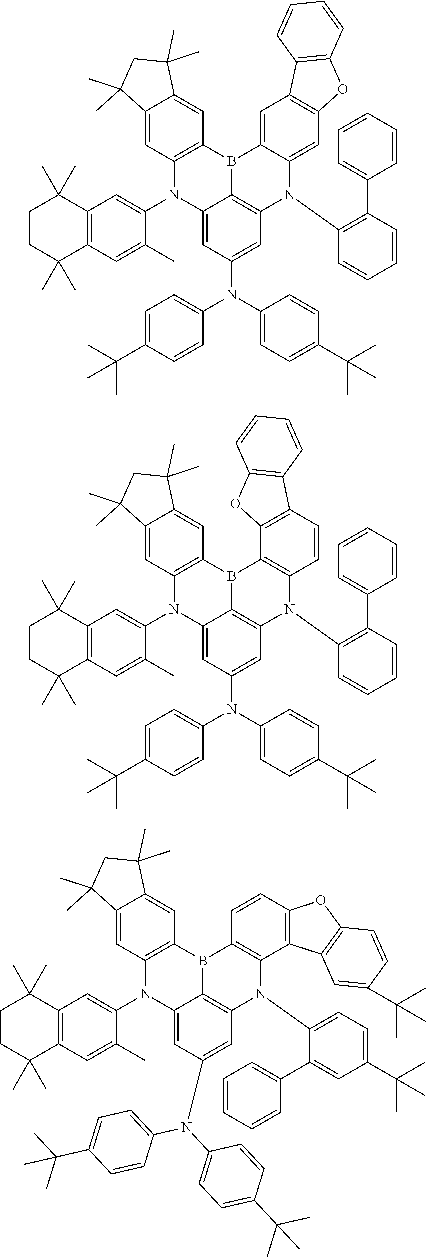

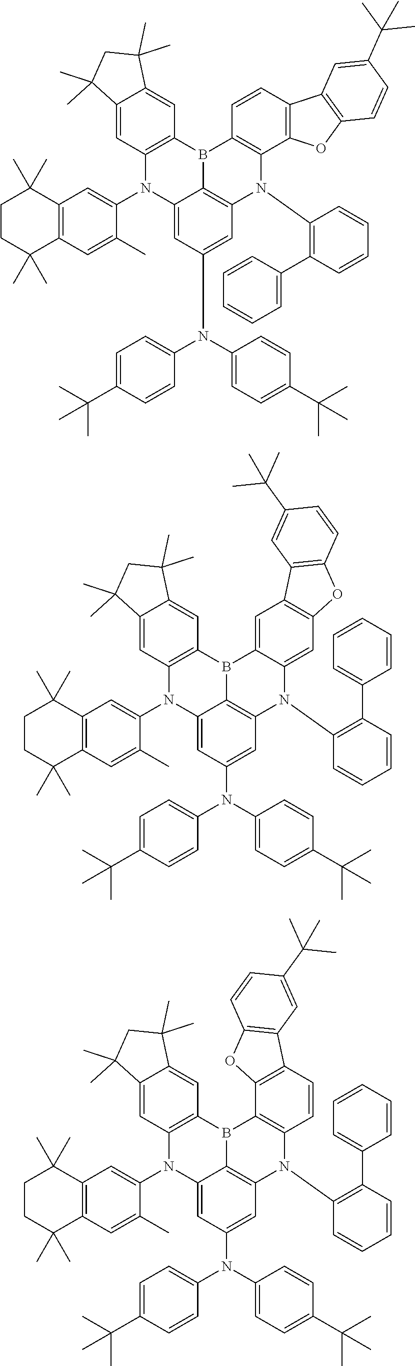

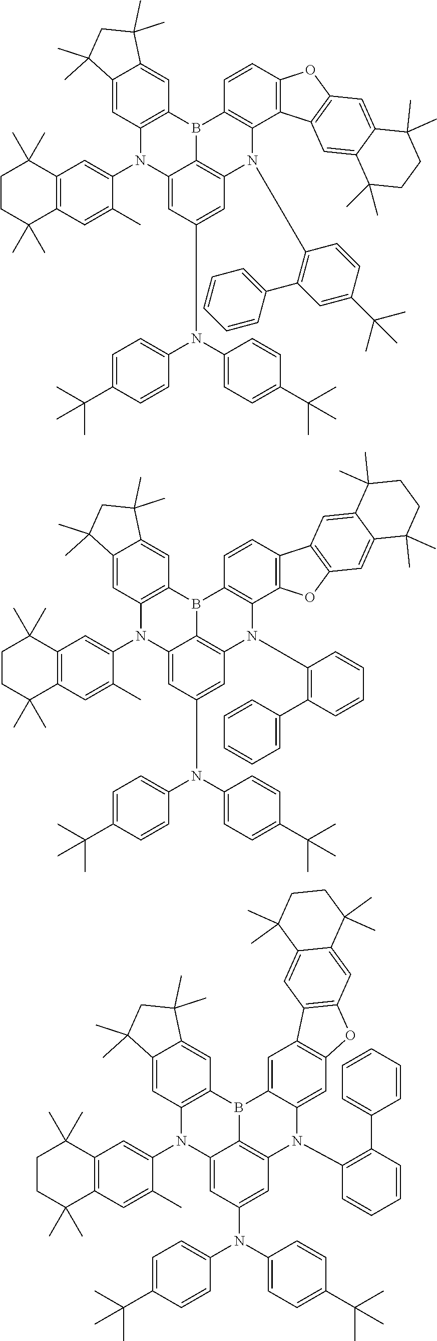

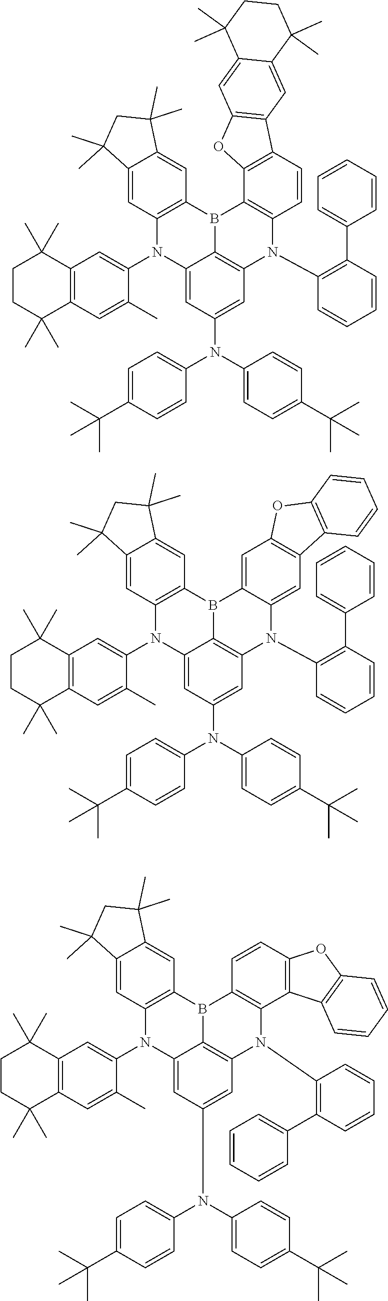

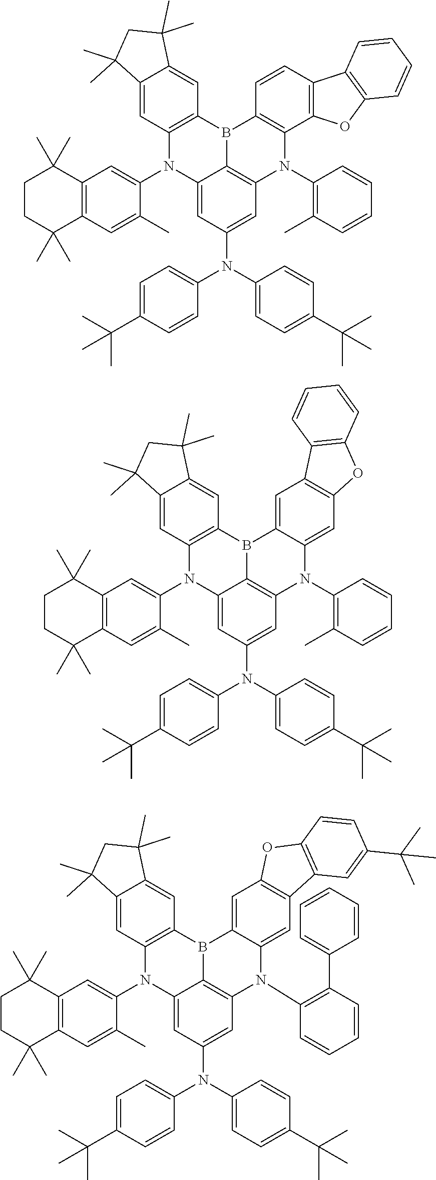

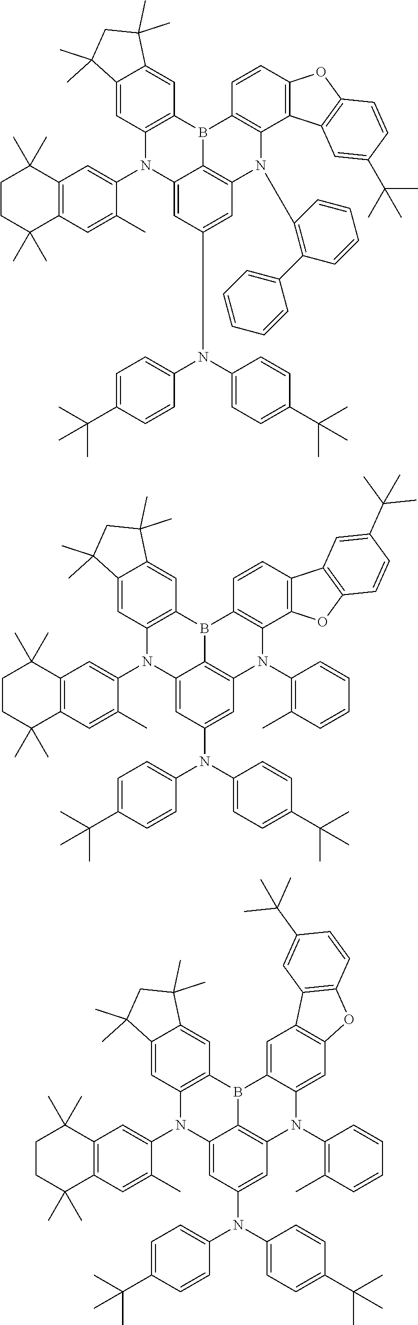

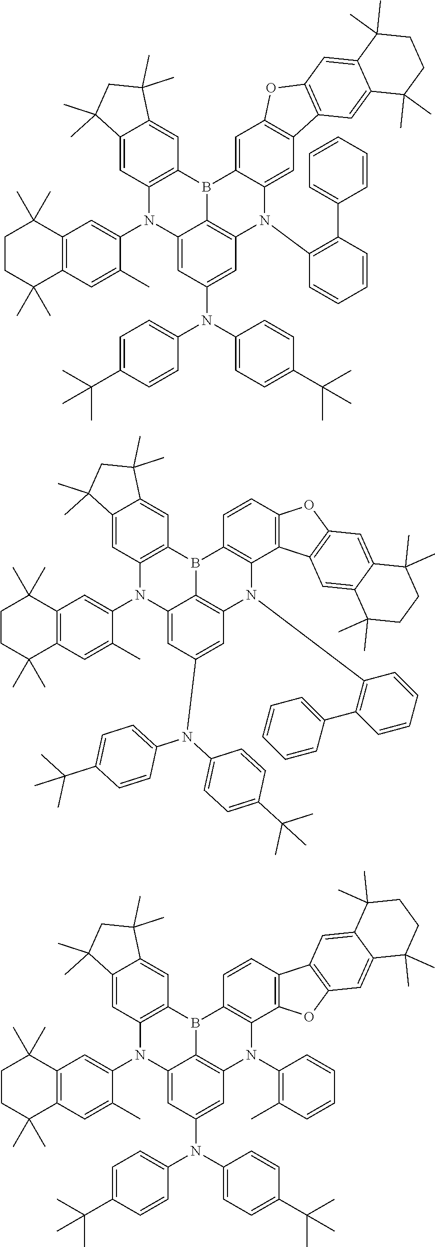 [SMILES: Cc1cc2c(cc1N1c3cc4c(cc3B3c5cc6oc7cc8c(cc7c6cc5N(c5ccccc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6oc7cc8c(cc7c6c5N(c5ccccc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C]

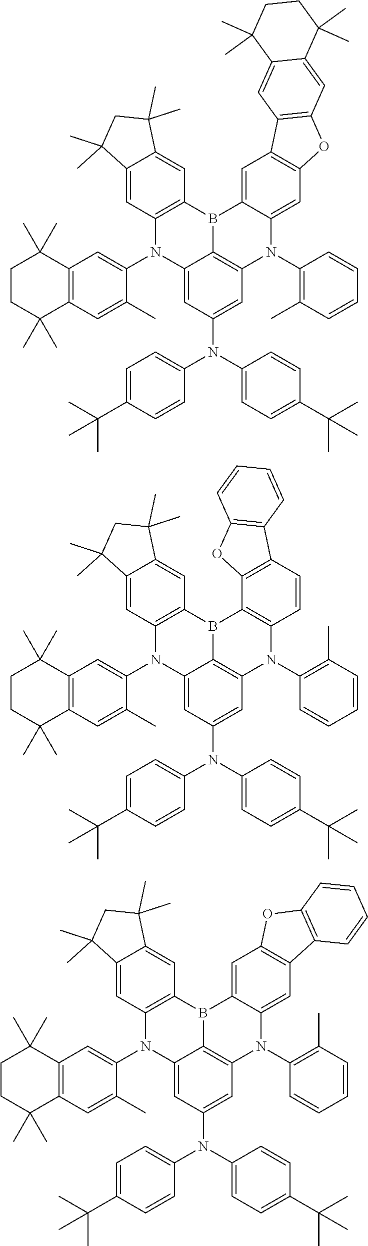

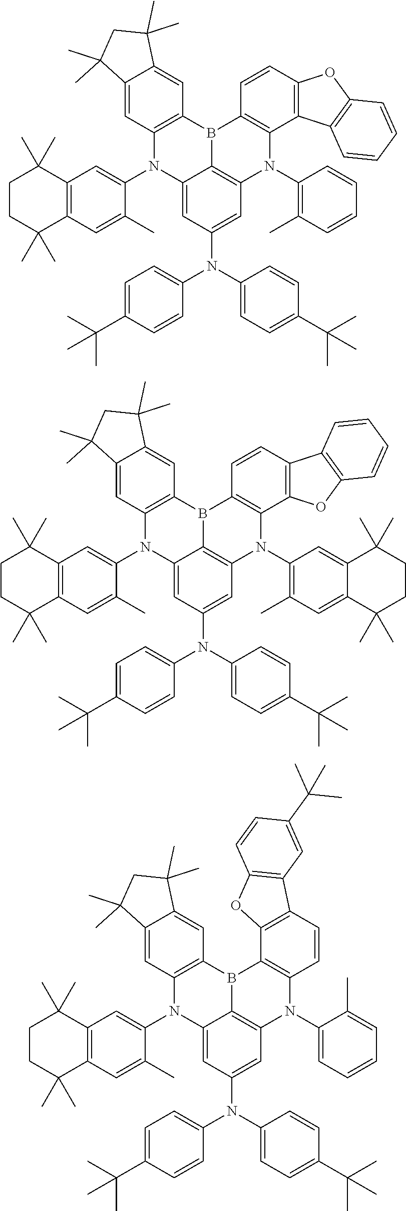

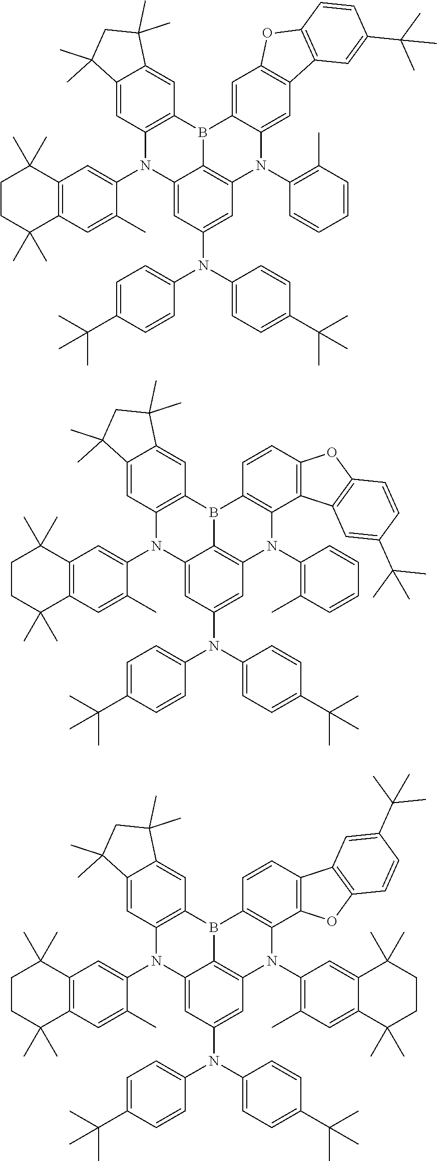 [SMILES: Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)CC5(C)C)oc1ccc(C(C)(C)C)cc13 ; Cc1cc2c(cc1N1c3cc4c(cc3B3c5ccc6oc7ccc(C(C)(C)C)cc7c6c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C]

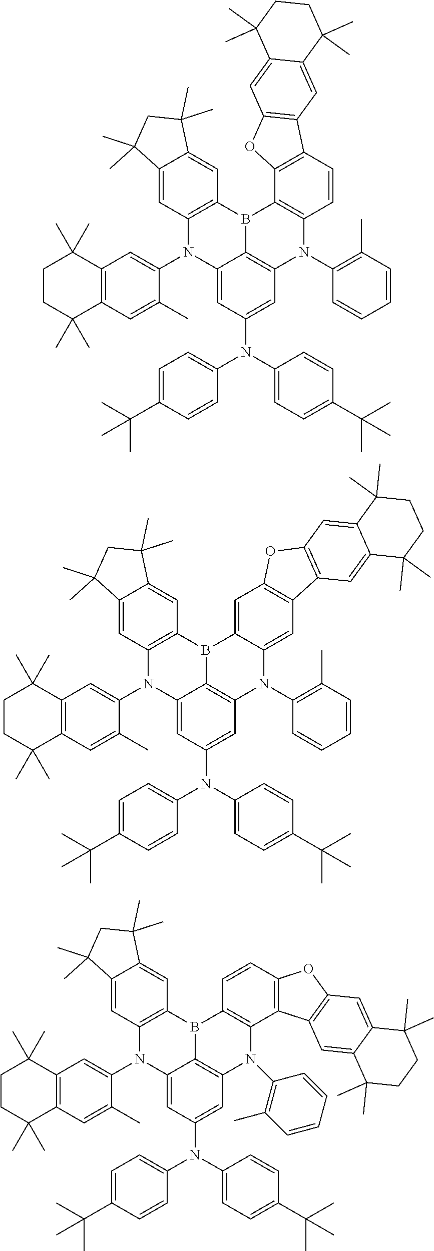

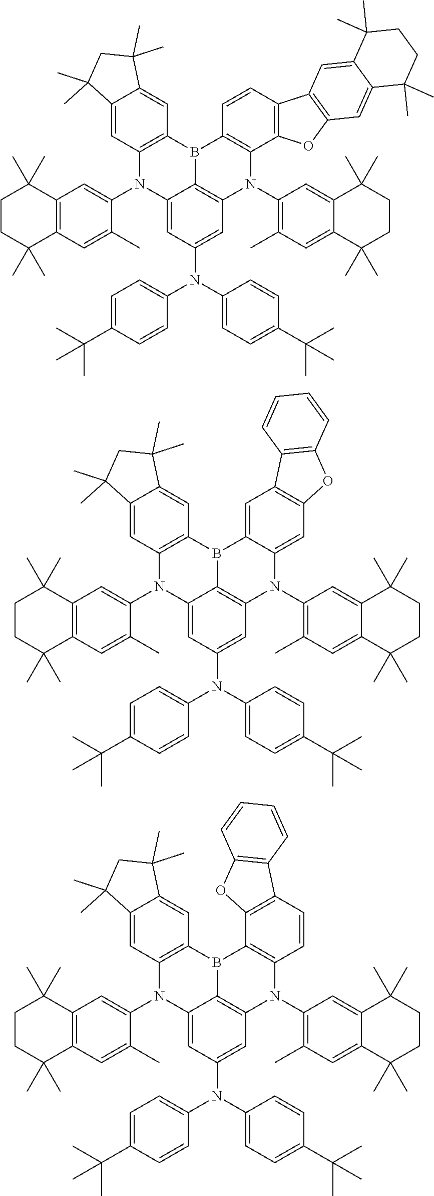

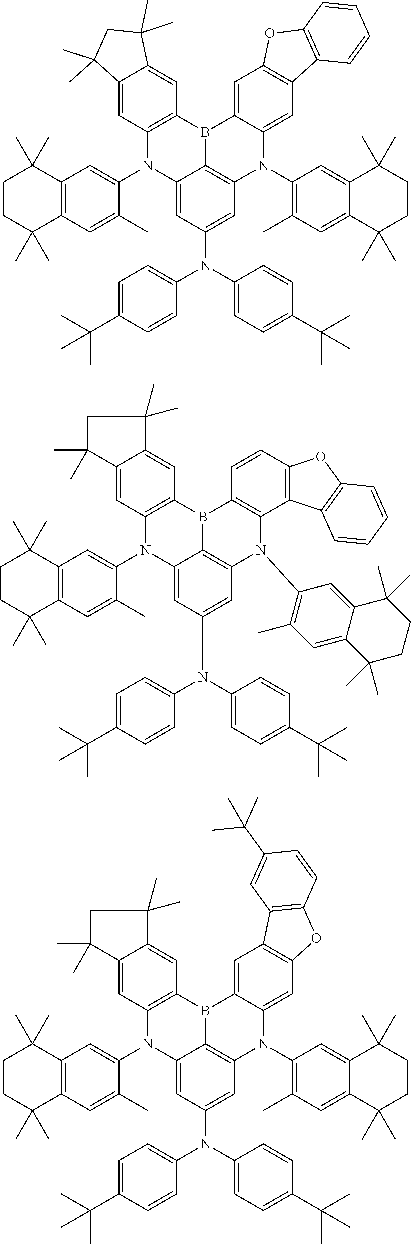 [SMILES: Cc1cc2c(cc1N1c3cc4c(cc3B3c5cc6oc7ccccc7c6cc5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6oc7ccccc7c6c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)oc1ccc(C(C)(C)C)cc16)C(C)(C)CC4(C)C)C(C)(C)CCC2(C)C]

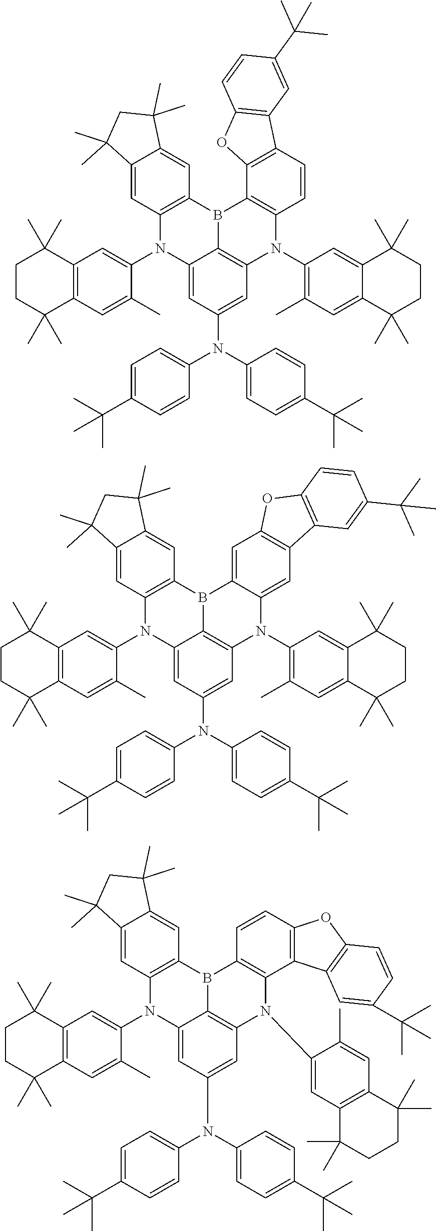

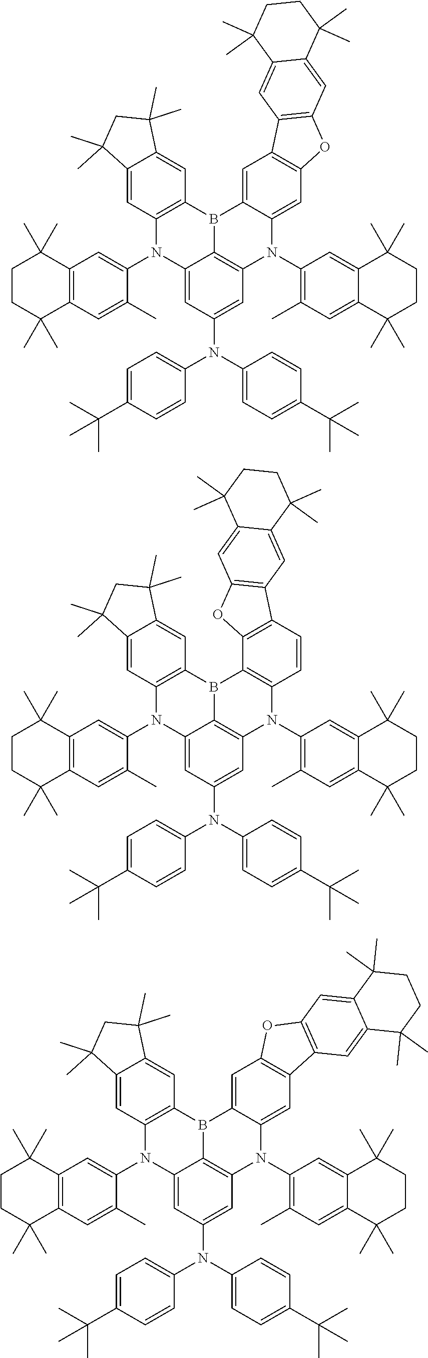

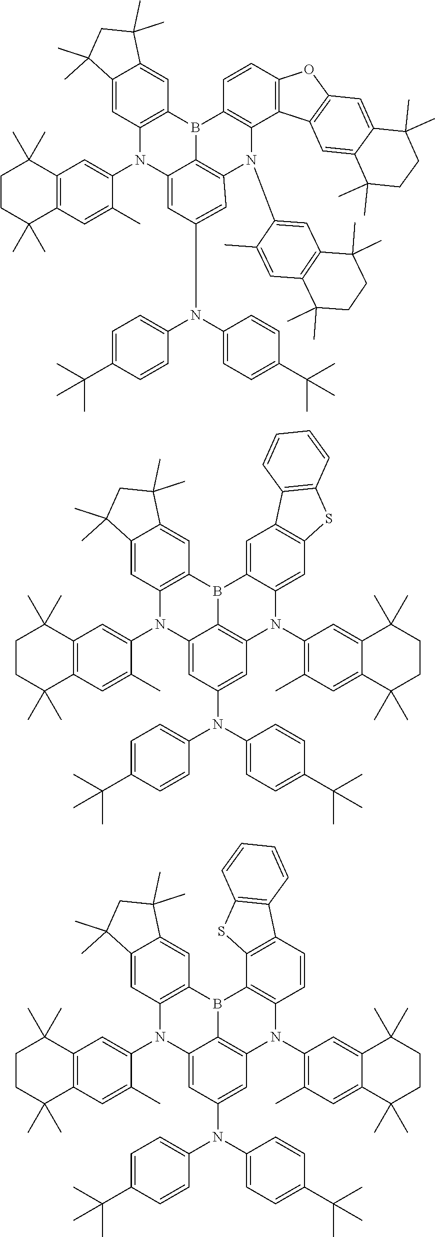

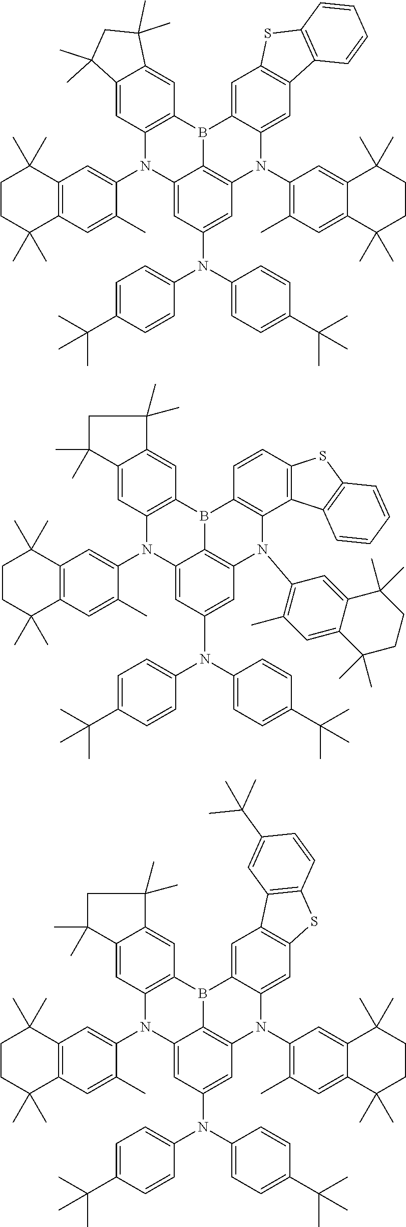 [SMILES: Cc1cc2c(cc1N1c3cc4c(cc3B3c5cc6sc7ccccc7c6cc5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6sc7ccccc7c6c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)sc1ccc(C(C)(C)C)cc16)C(C)(C)CC4(C)C)C(C)(C)CCC2(C)C]

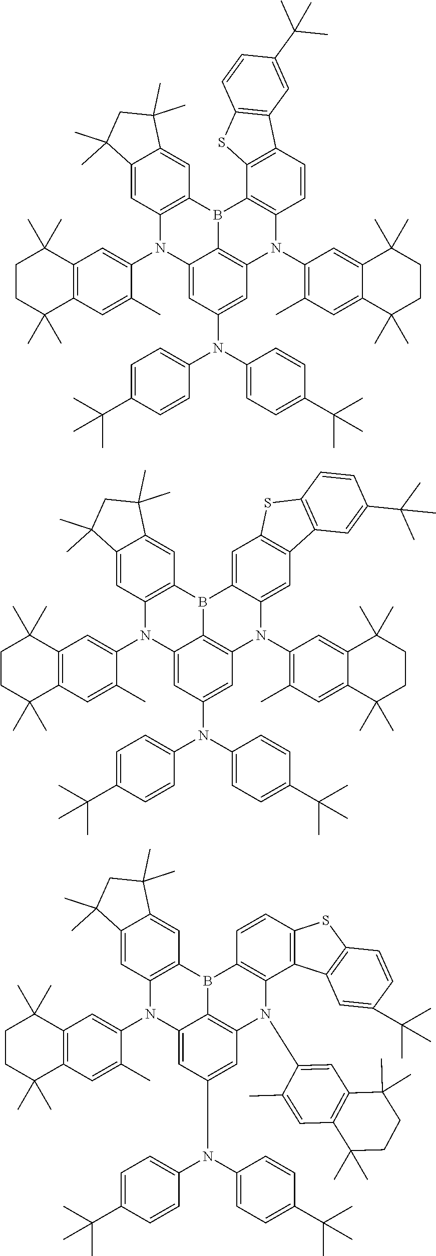

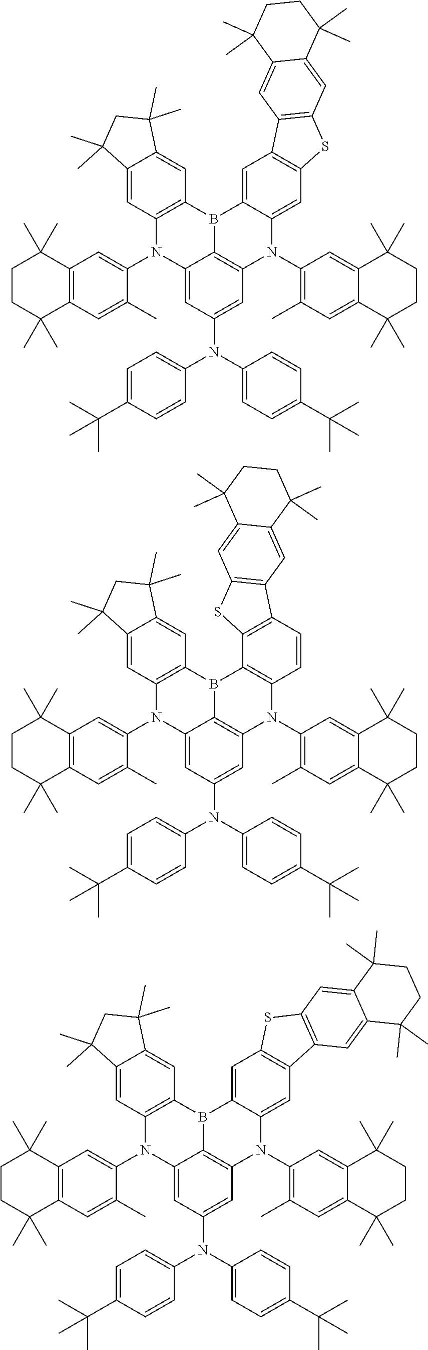

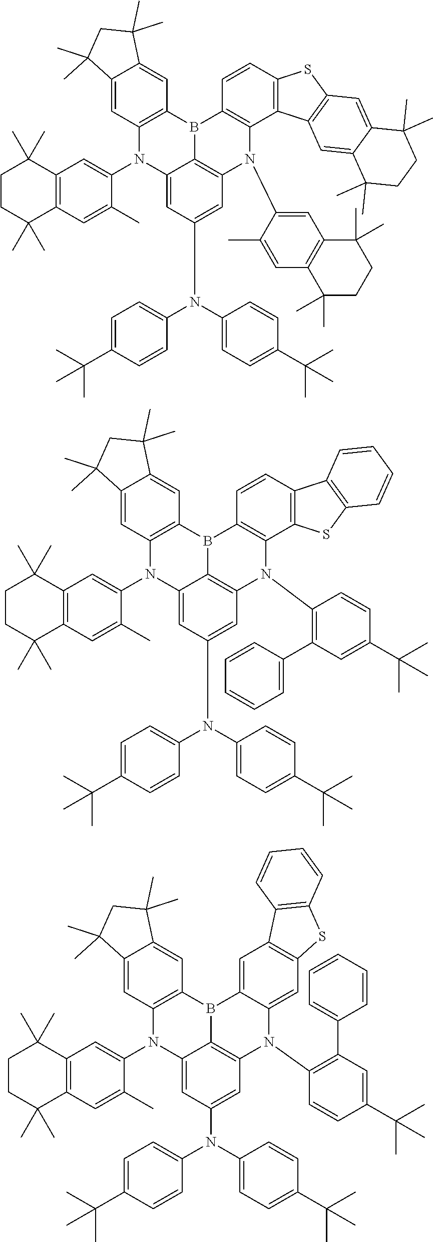

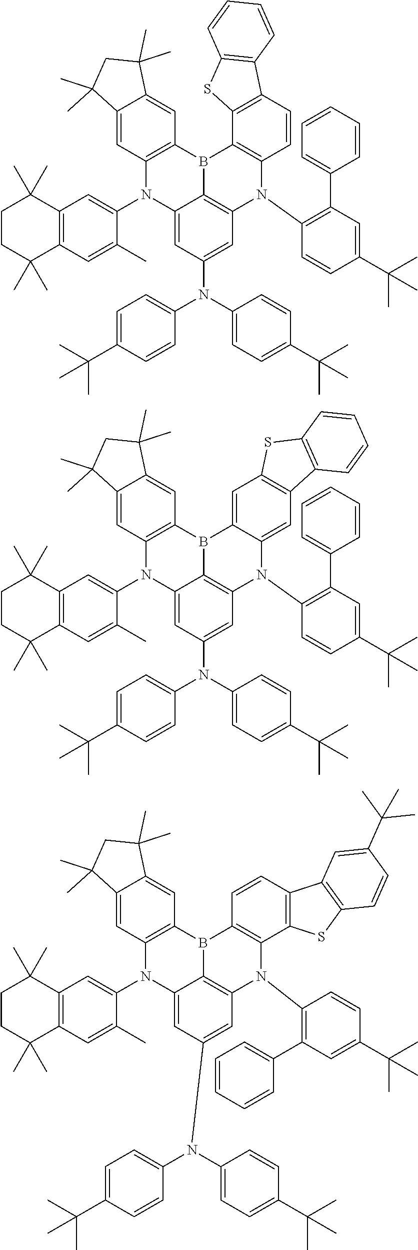

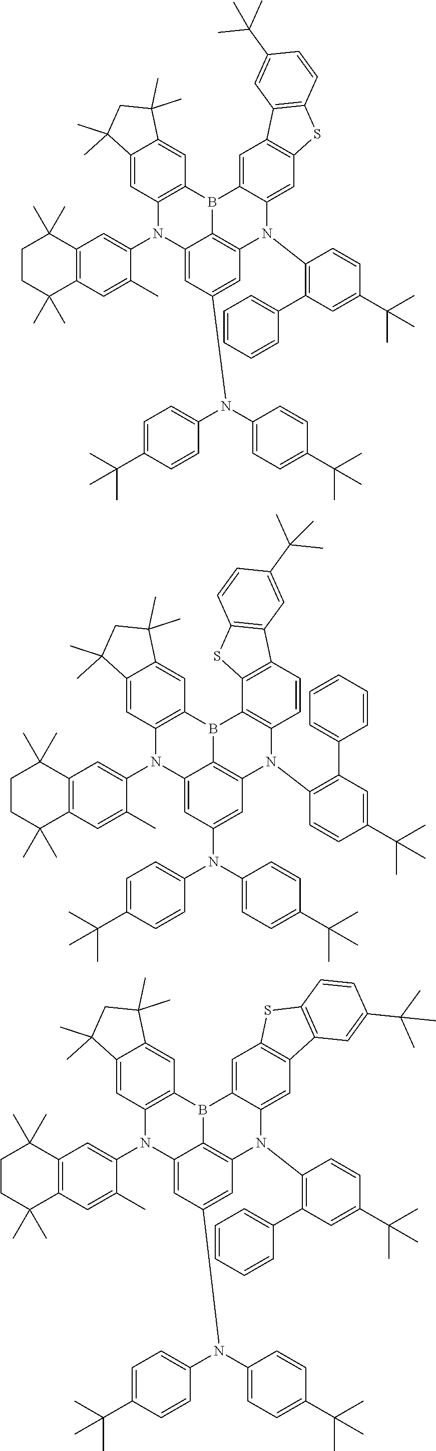

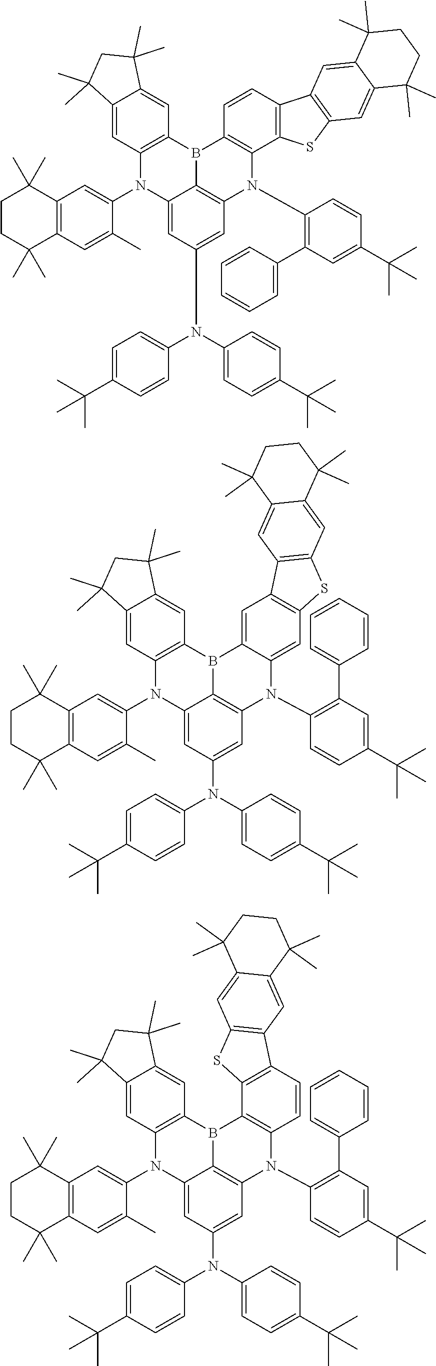

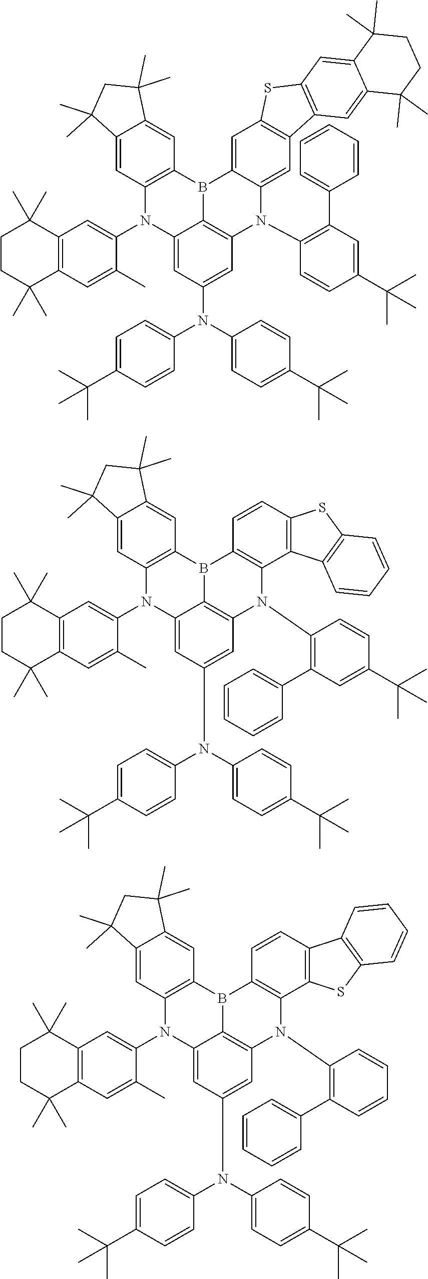 [SMILES: Cc1cc2c(cc1N1c3cc4c(cc3B3c5cc6sc7cc8c(cc7c6cc5N(c5ccc(C(C)(C)C)cc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6sc7ccccc7c6c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C]

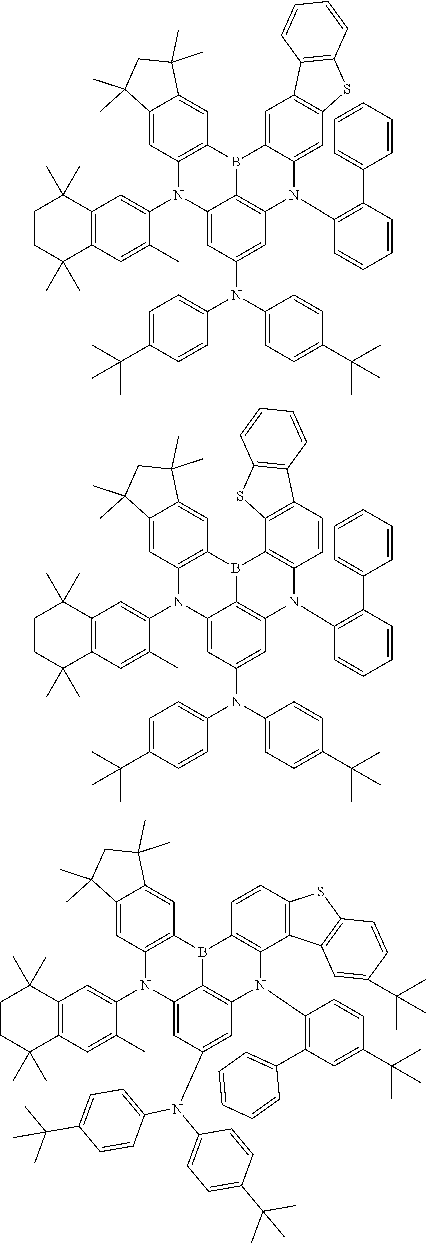

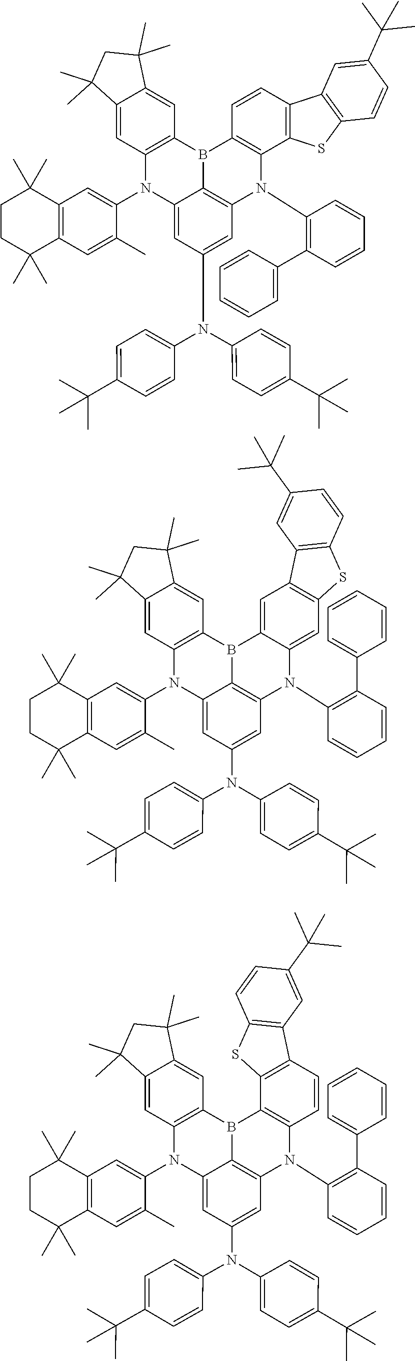

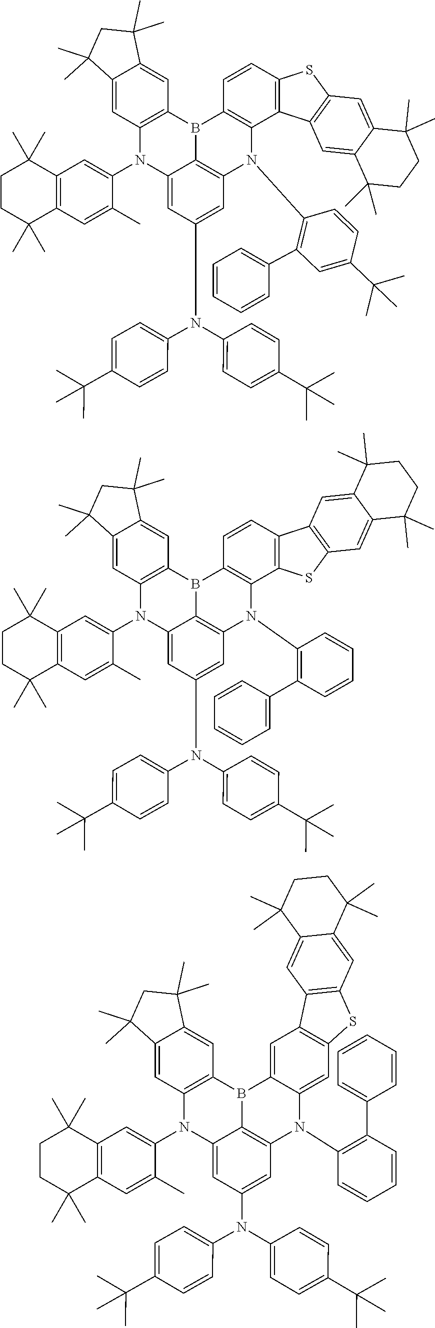

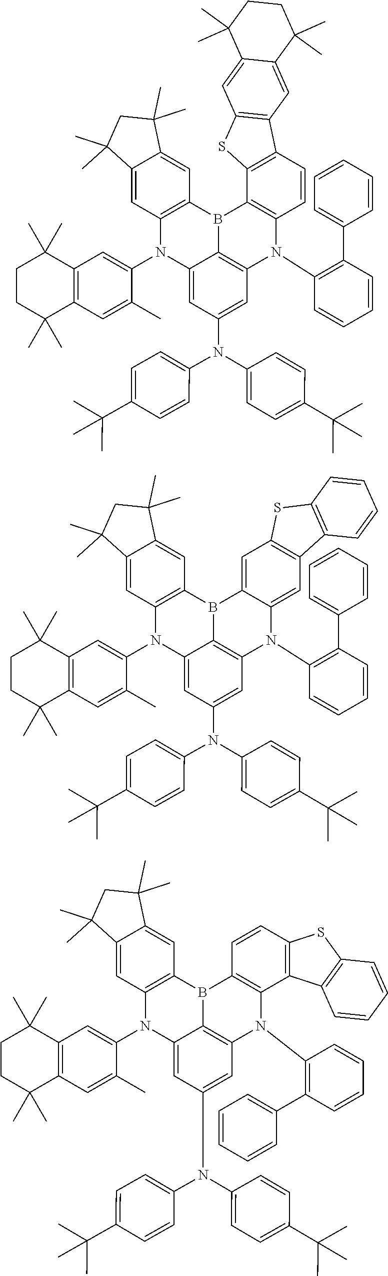

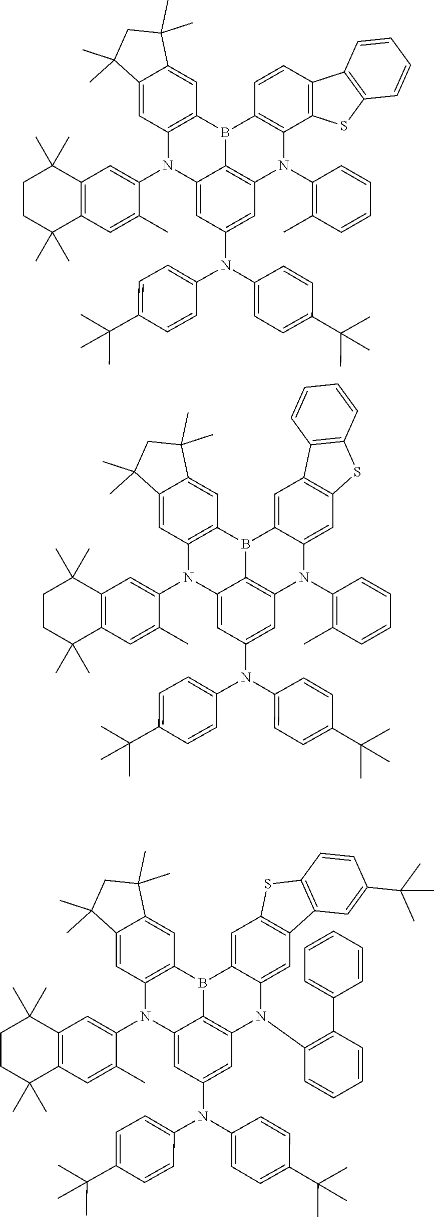

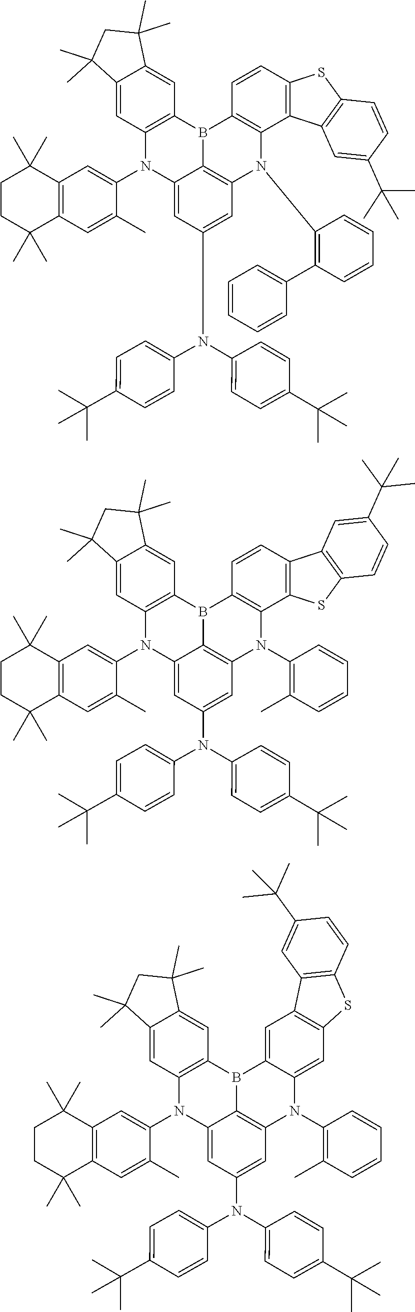

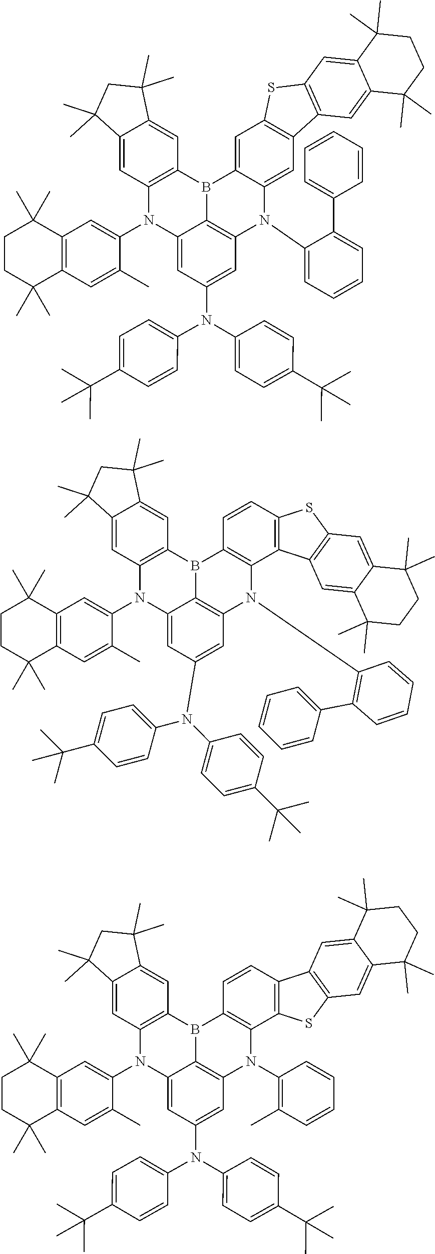 [SMILES: Cc1cc2c(cc1N1c3cc4c(cc3B3c5cc6sc7cc8c(cc7c6cc5N(c5ccccc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C]

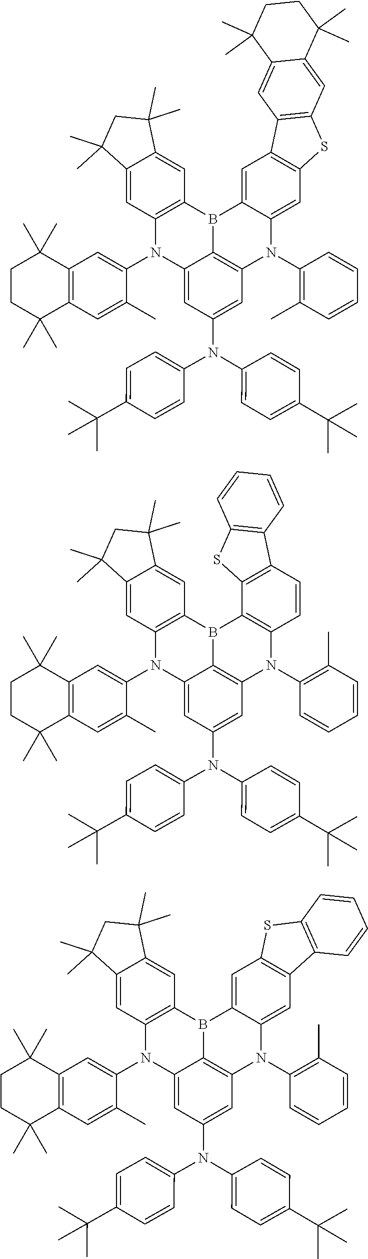

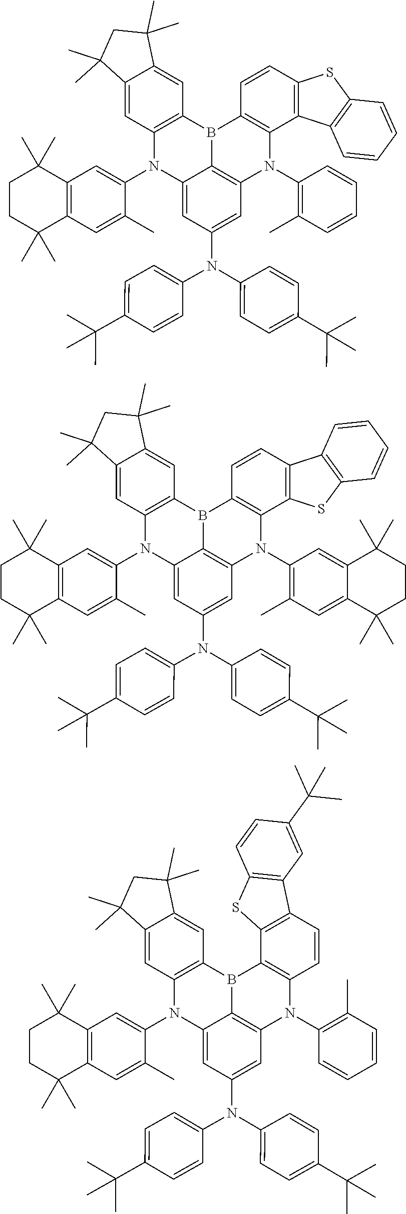

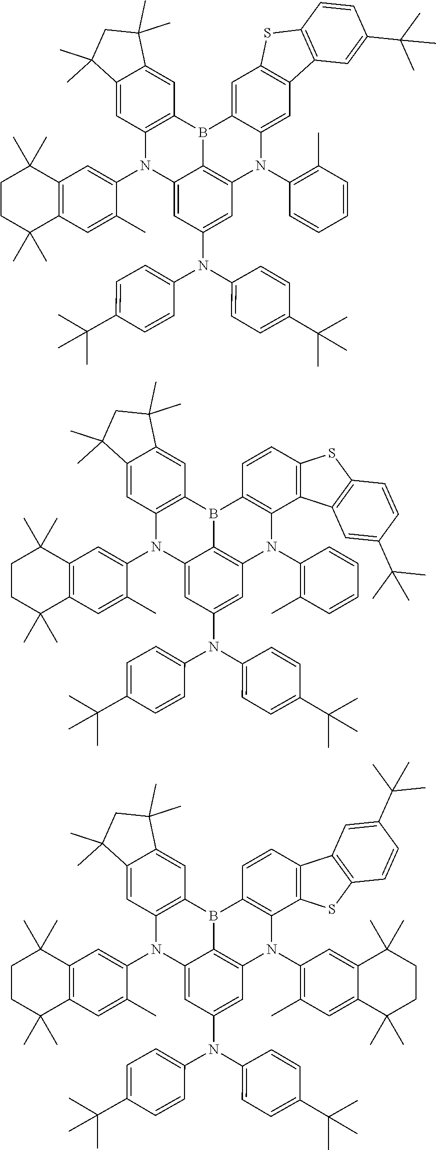

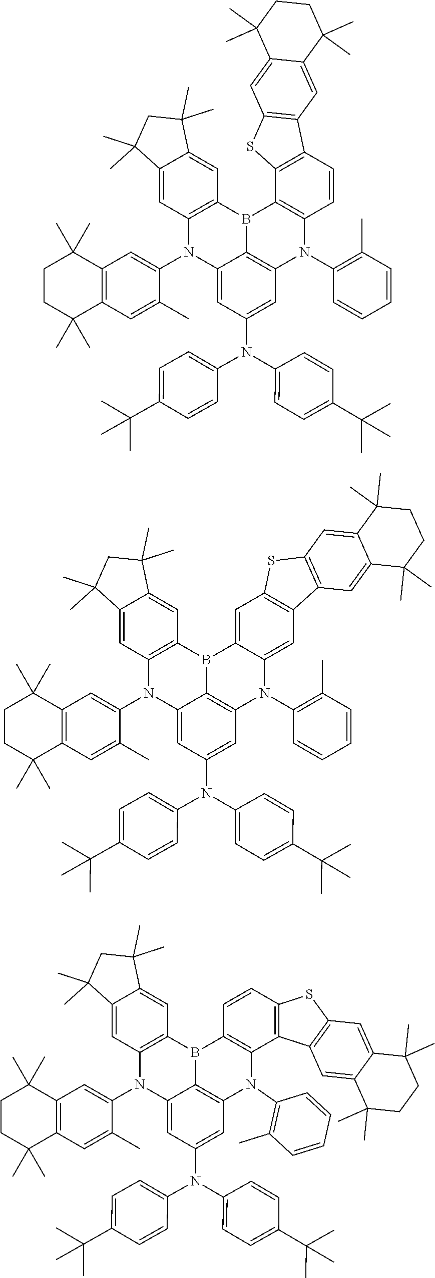

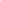

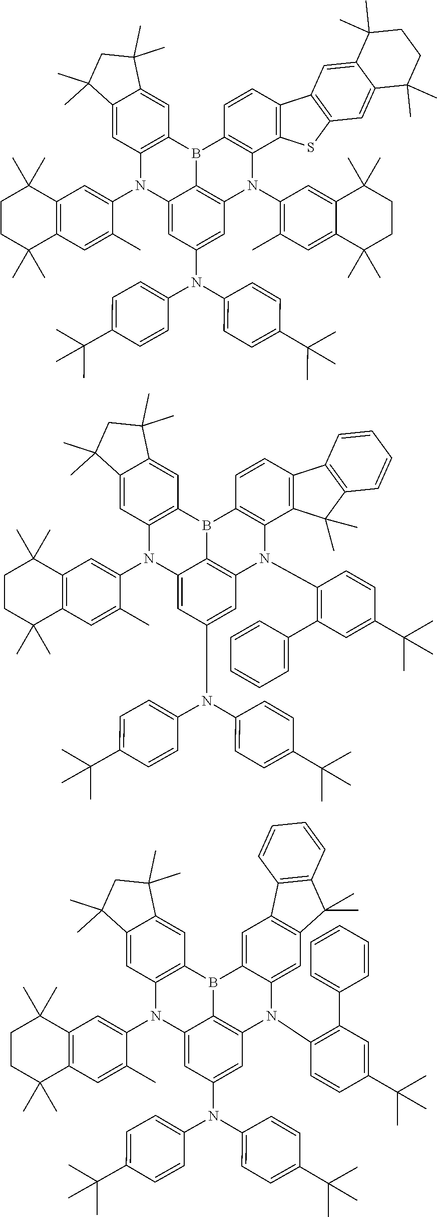

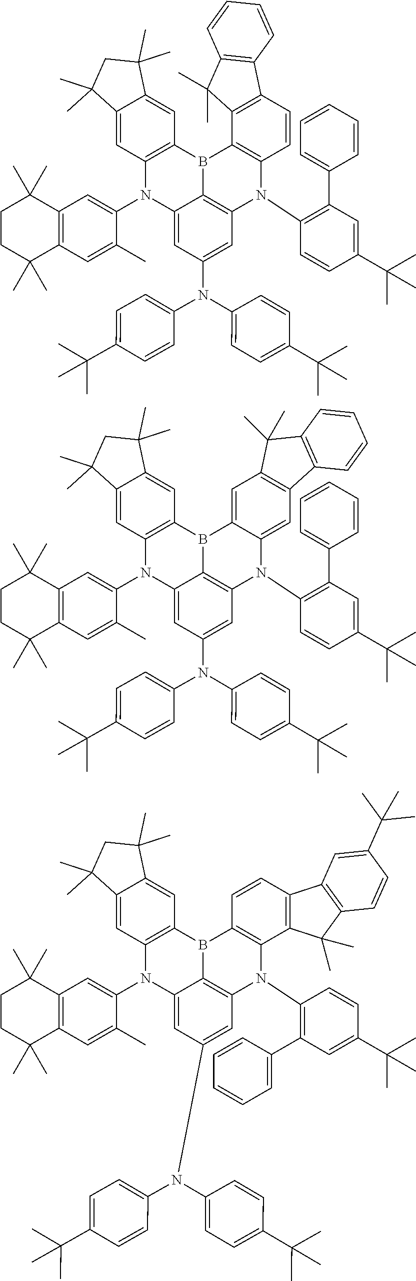

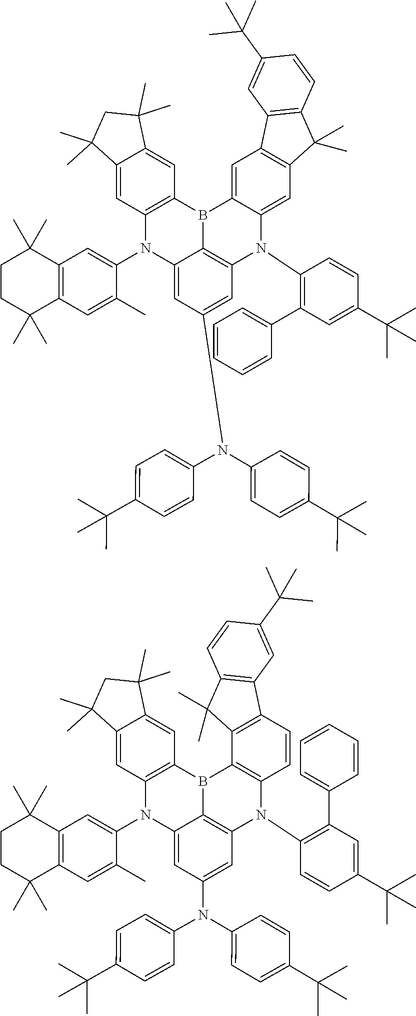

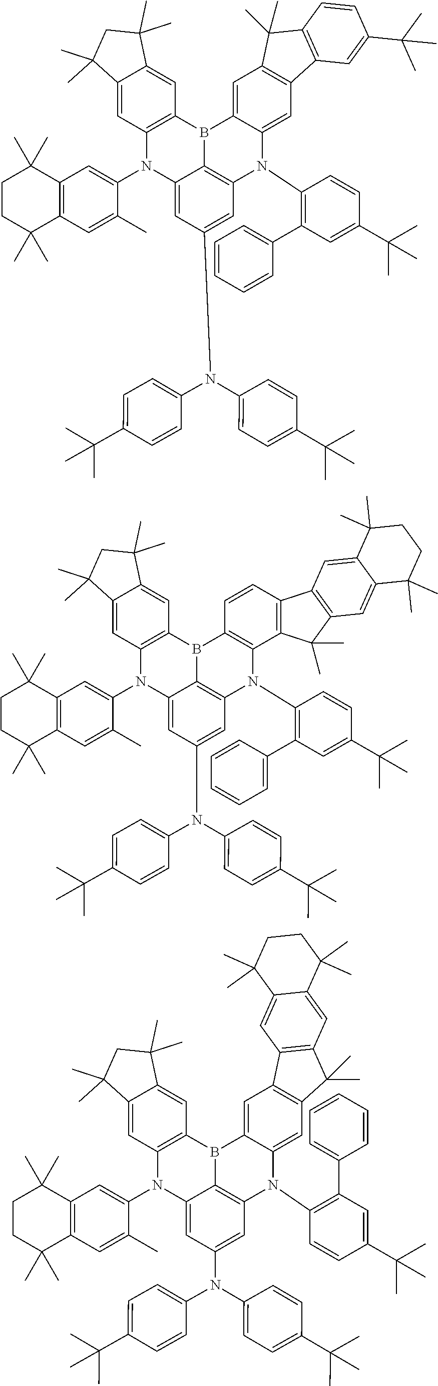

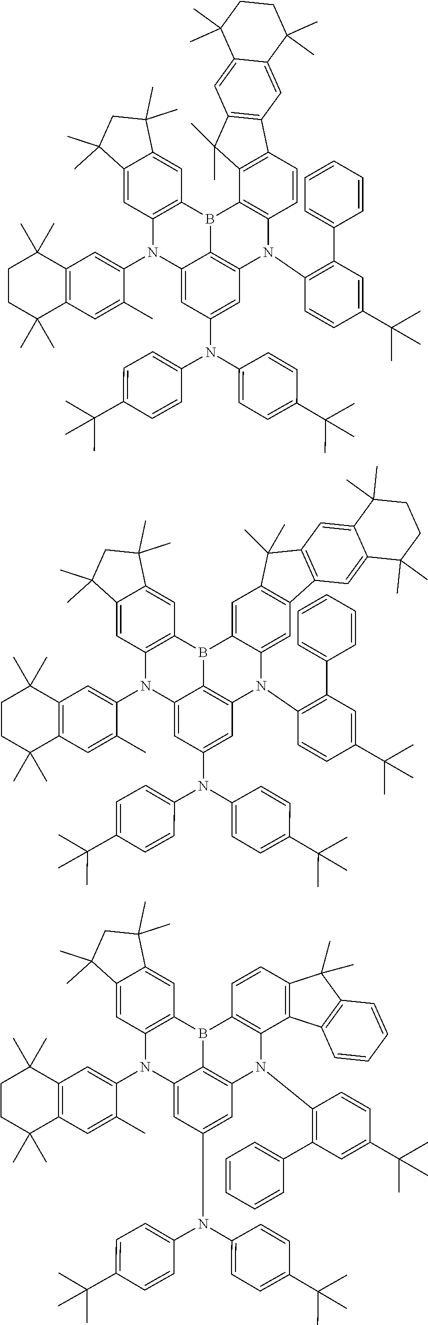

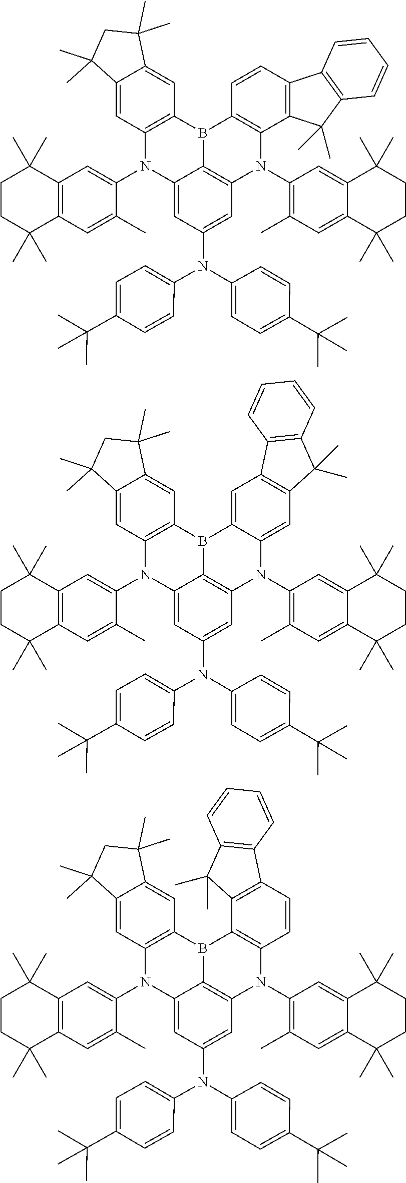

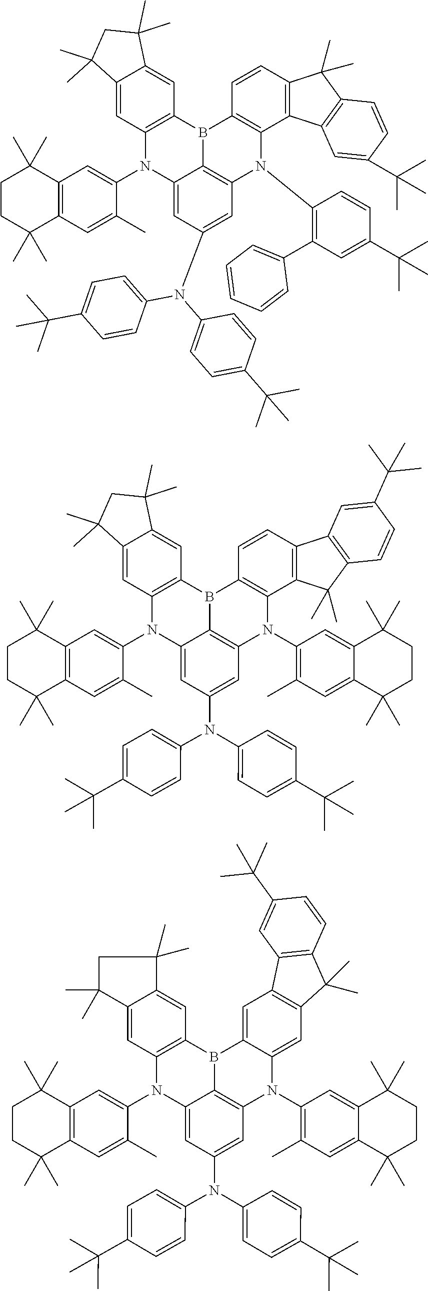

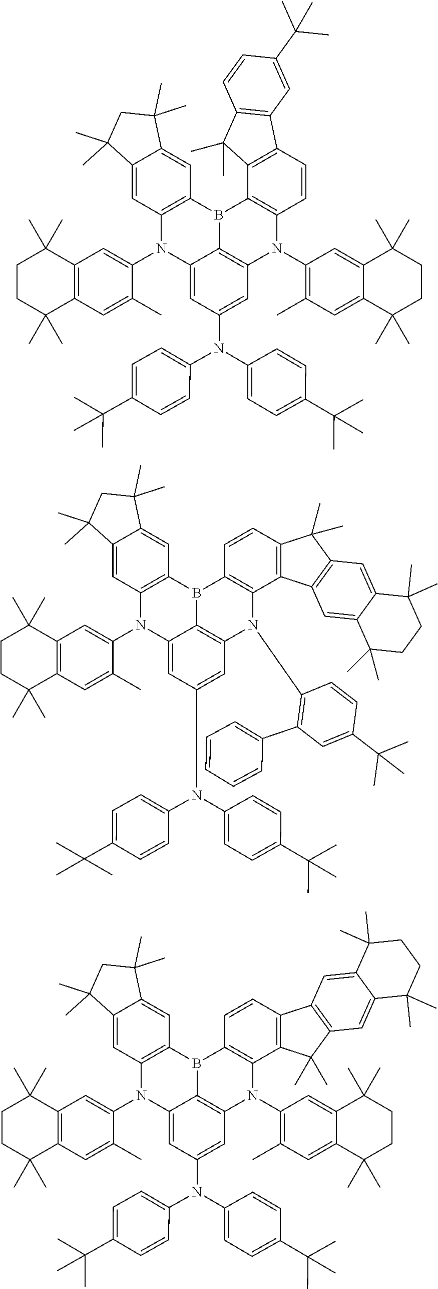

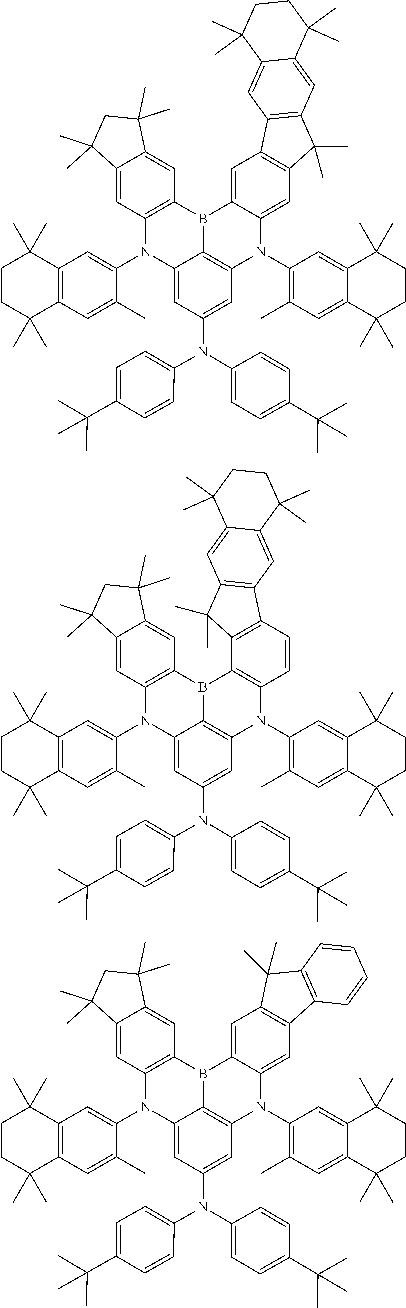

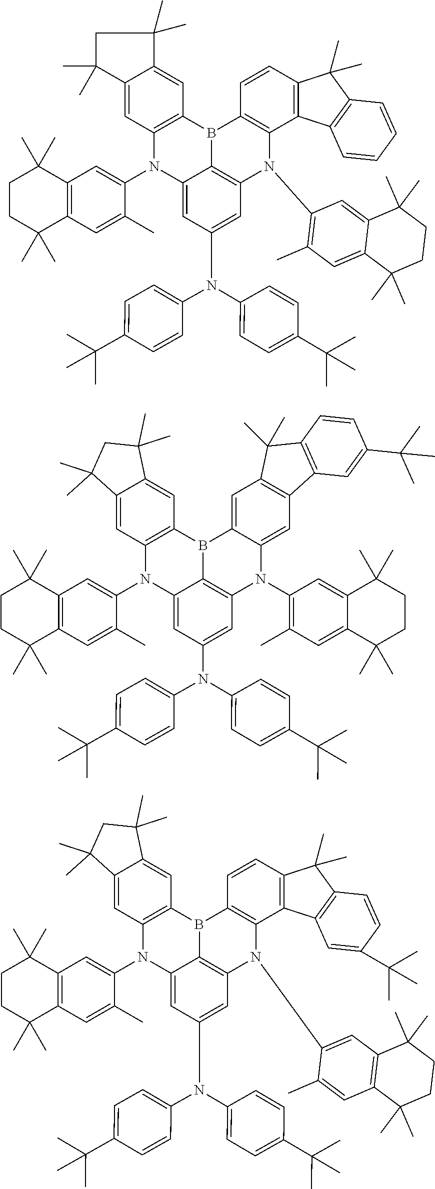

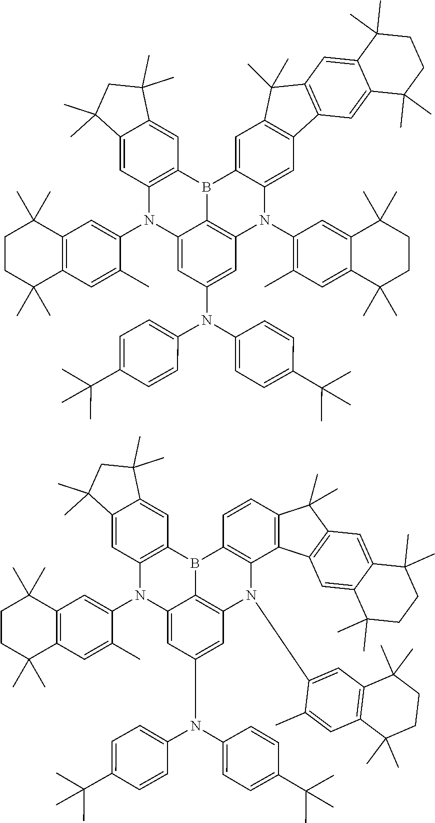

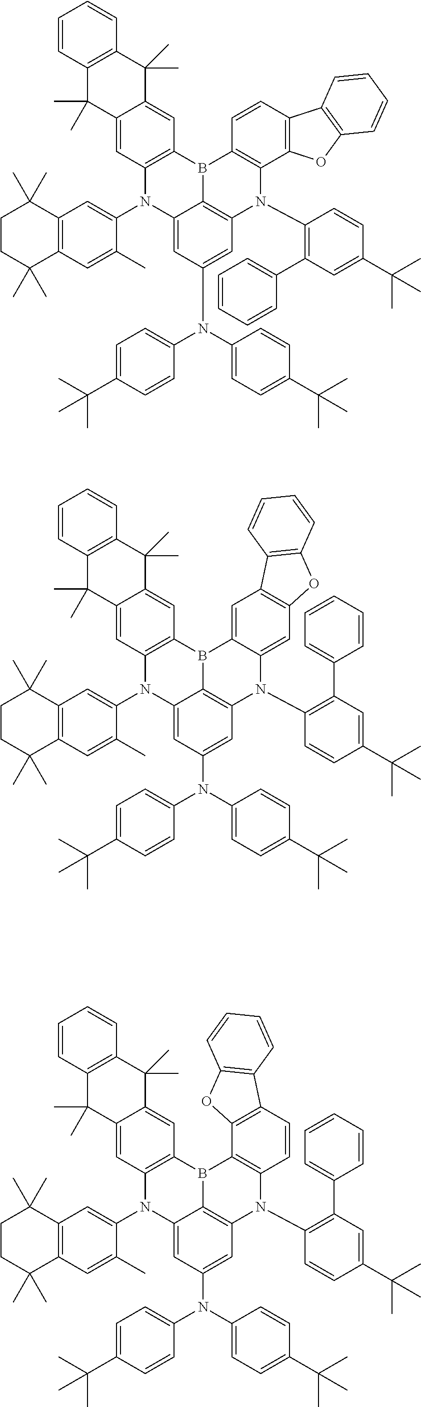

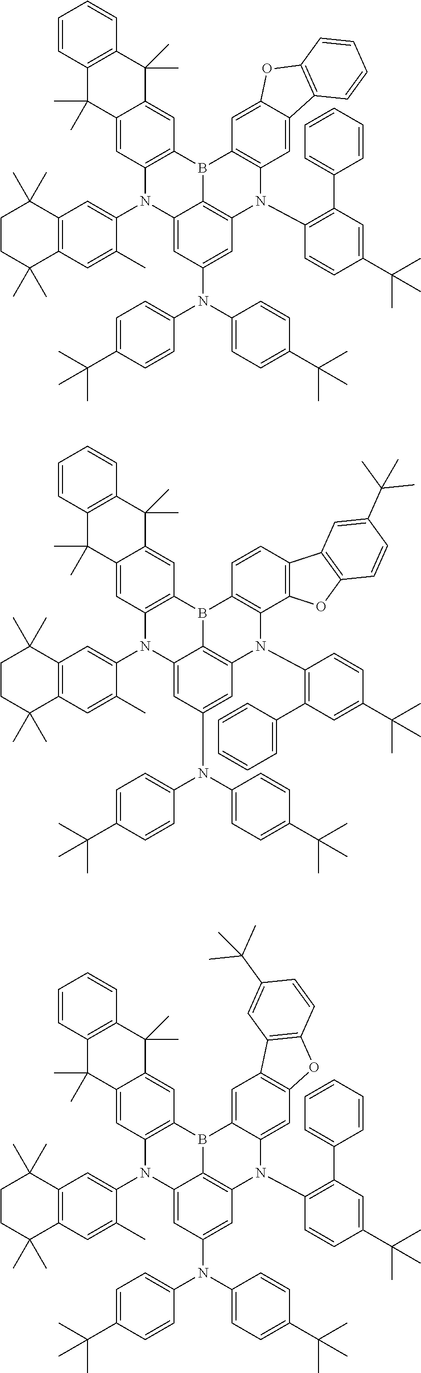

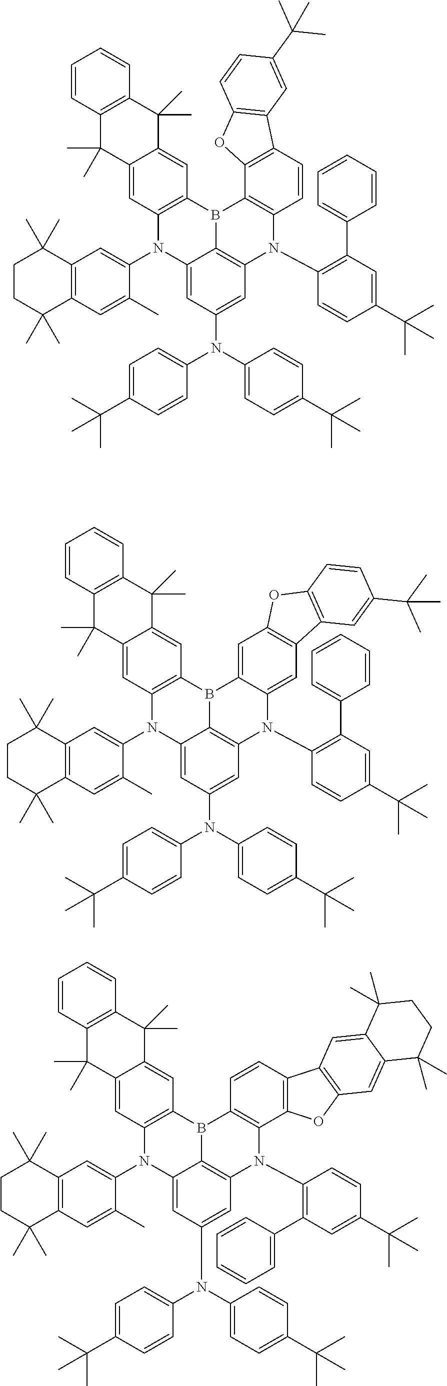

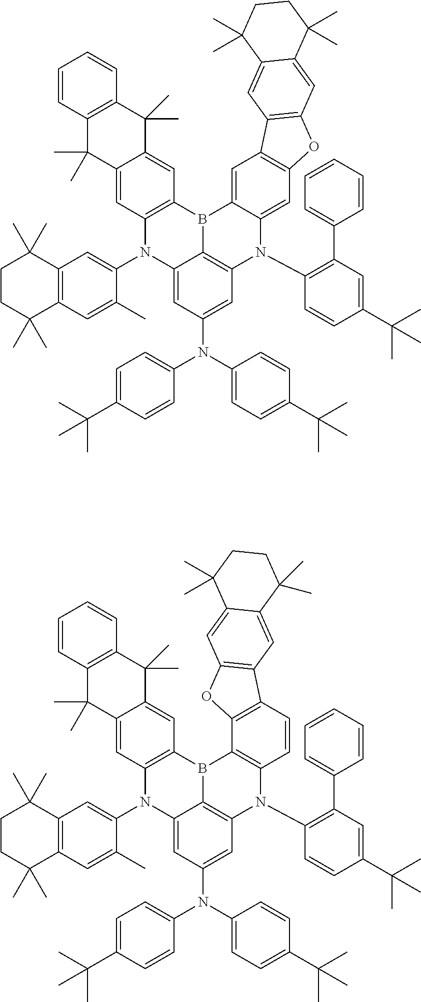 [SMILES: Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccc(C(C)(C)C)cc1-c1ccccc1)c1ccc5c(oc6cc7c(cc65)C(C)(C)CCC7(C)C)c13)C(C)(C)c1ccccc1C4(C)C)C(C)(C)CCC2(C)C]

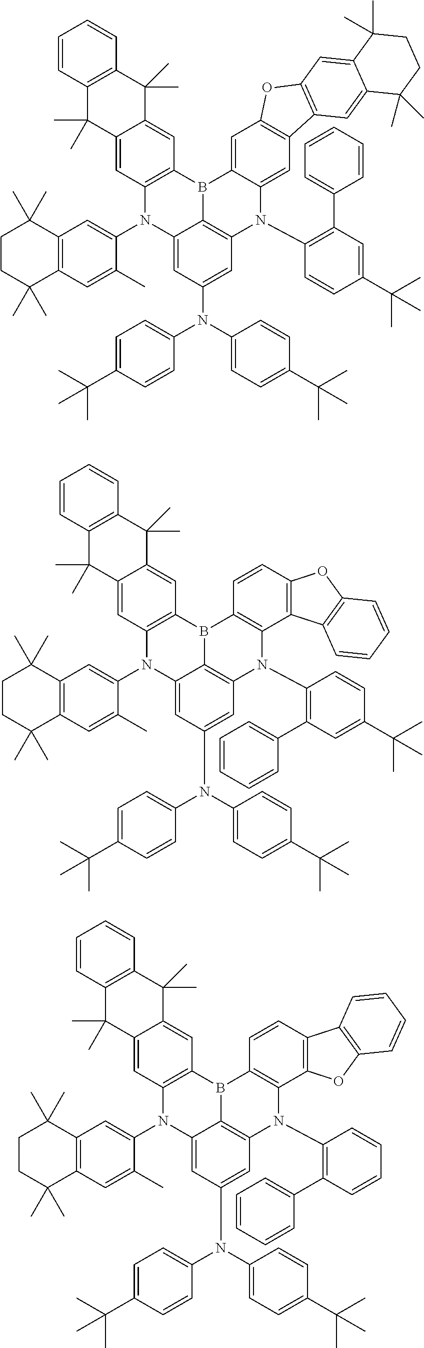

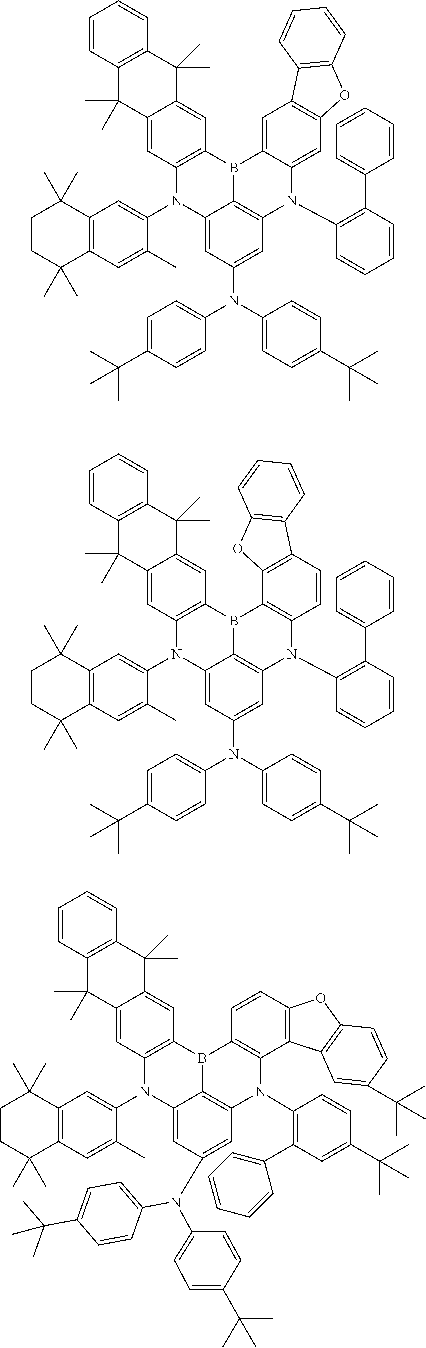 [SMILES: Cc1cc2c(cc1N1c3cc4c(cc3B3c5cc6c(cc5N(c5ccccc5-c5ccccc5)c5cc(N(c7ccc(C(C)(C)C)cc7)c7ccc(C(C)(C)C)cc7)cc1c53)oc1ccccc16)C(C)(C)c1ccccc1C4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccccc1-c1ccccc1)c1ccc5c(oc6ccccc65)c13)C(C)(C)c1ccccc1C4(C)C)C(C)(C)CCC2(C)C ; Cc1cc2c(cc1N1c3cc4c(cc3B3c5ccc6oc7ccc(C(C)(C)C)cc7c6c5N(c5ccc(C(C)(C)C)cc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

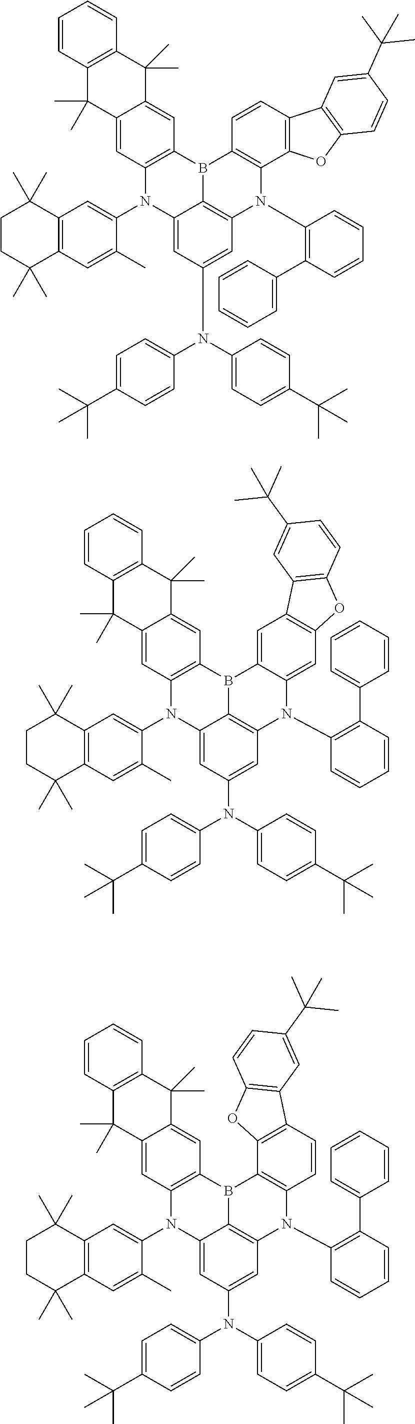

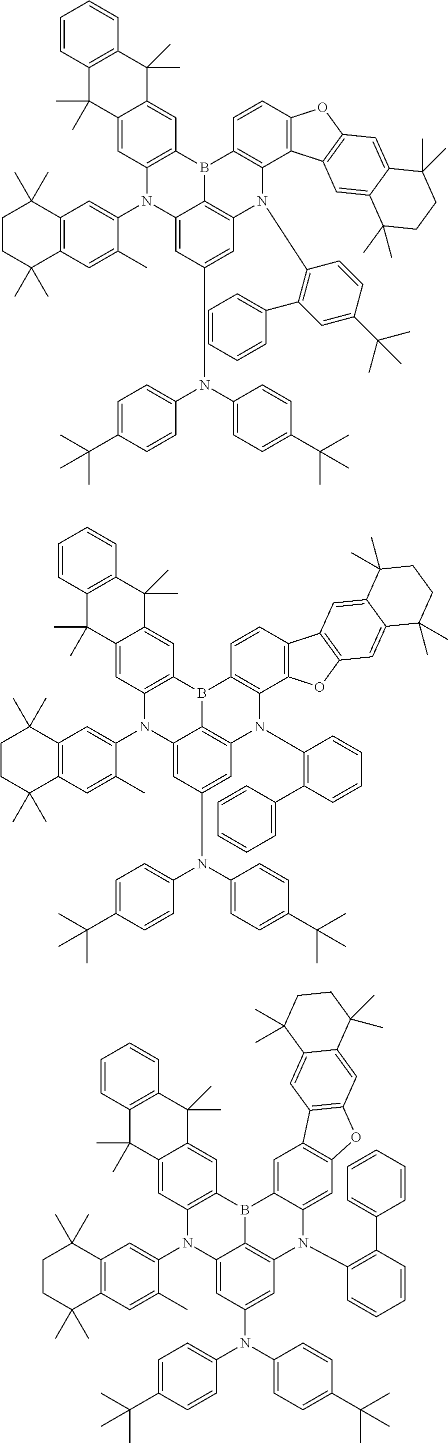

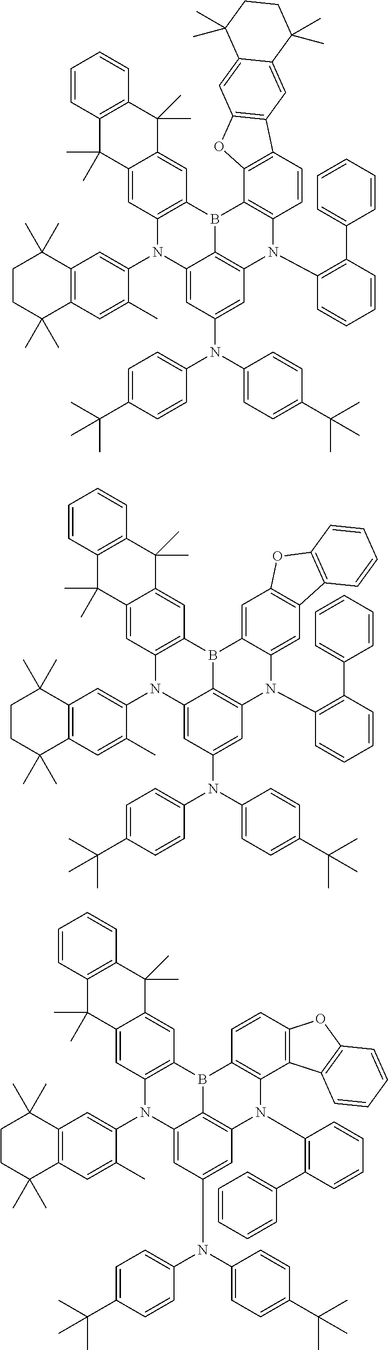

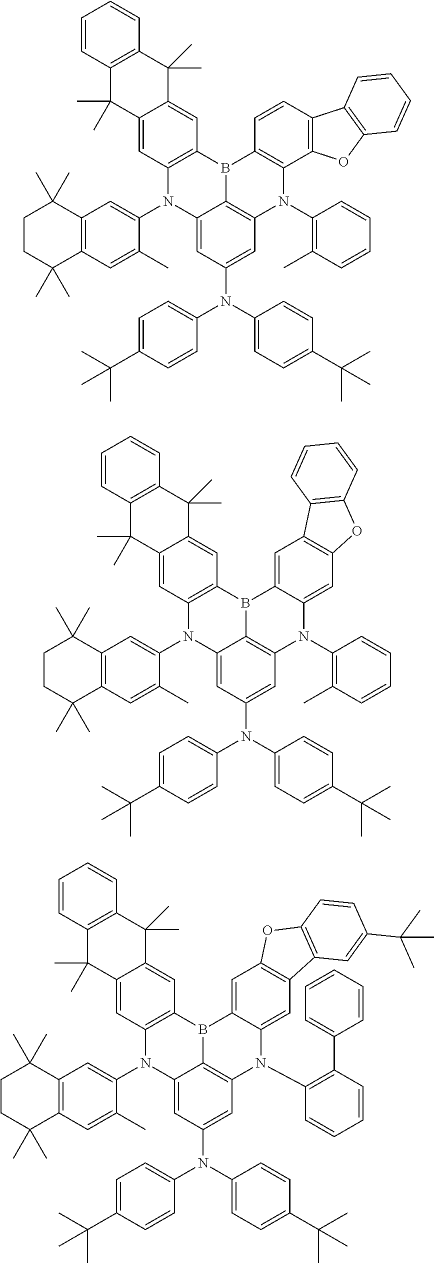

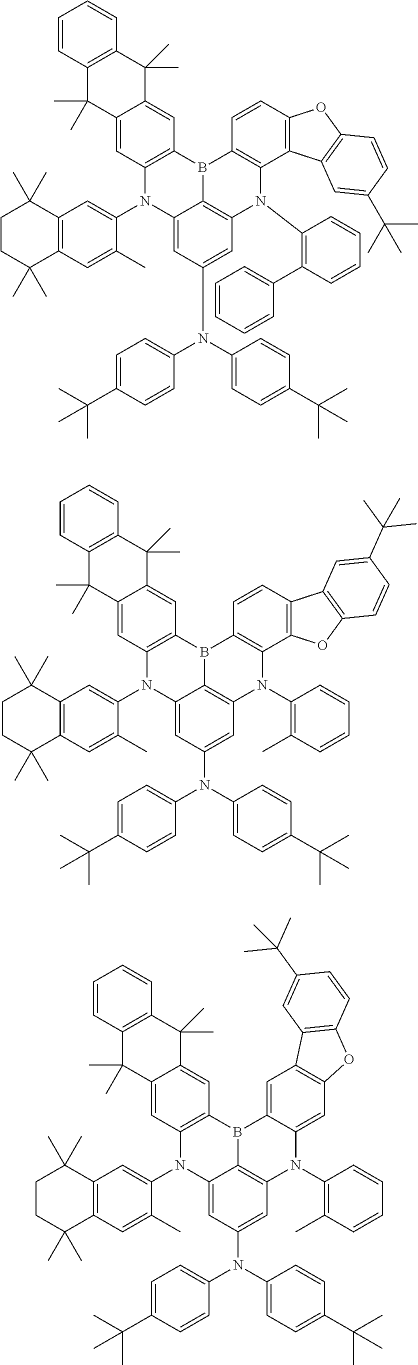

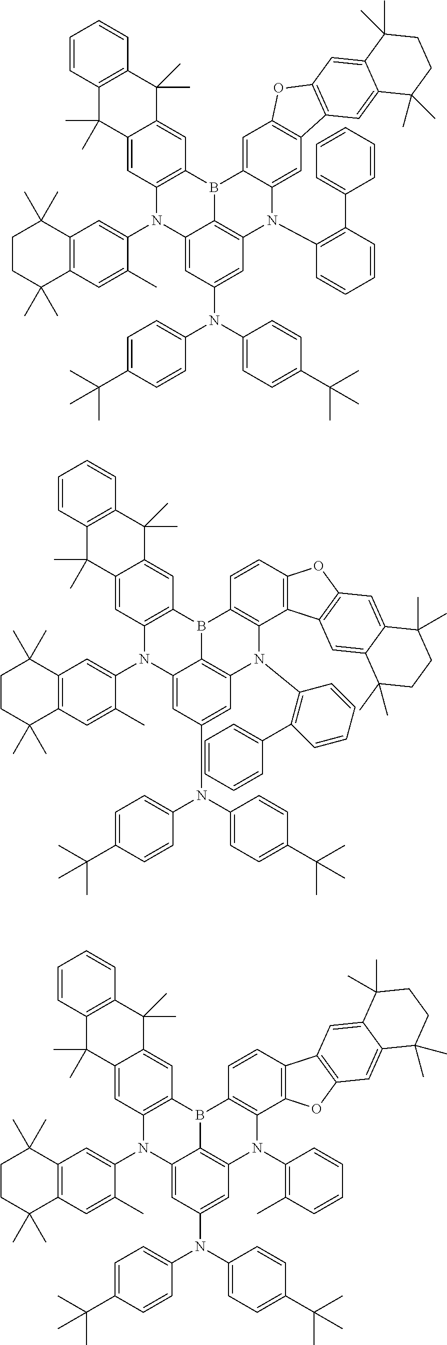

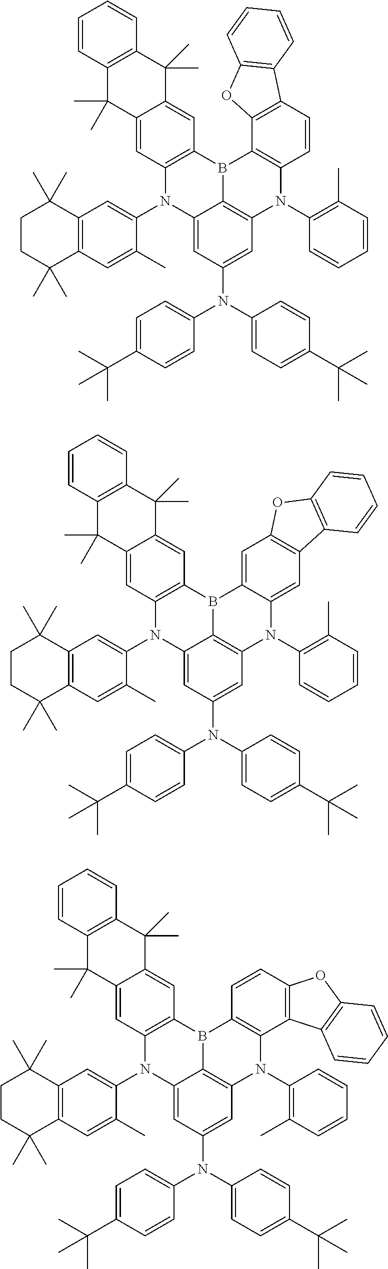

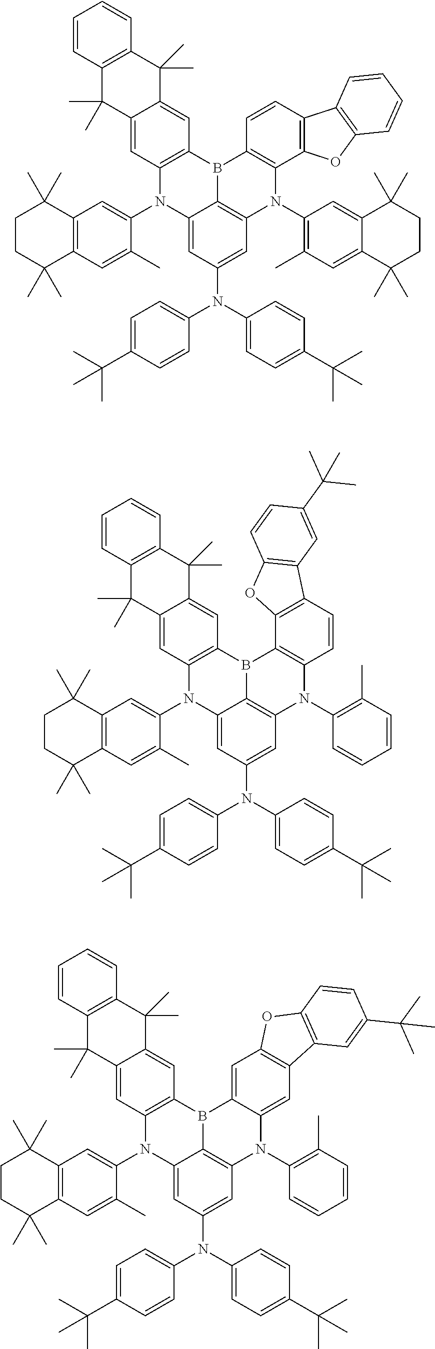 [SMILES: Cc1cc2c(cc1N1c3cc4c(cc3B3c5ccc6c(oc7ccccc76)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccccc1C)c1ccc5c(oc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)c1ccccc1C5(C)C)oc1ccc(C(C)(C)C)cc13]

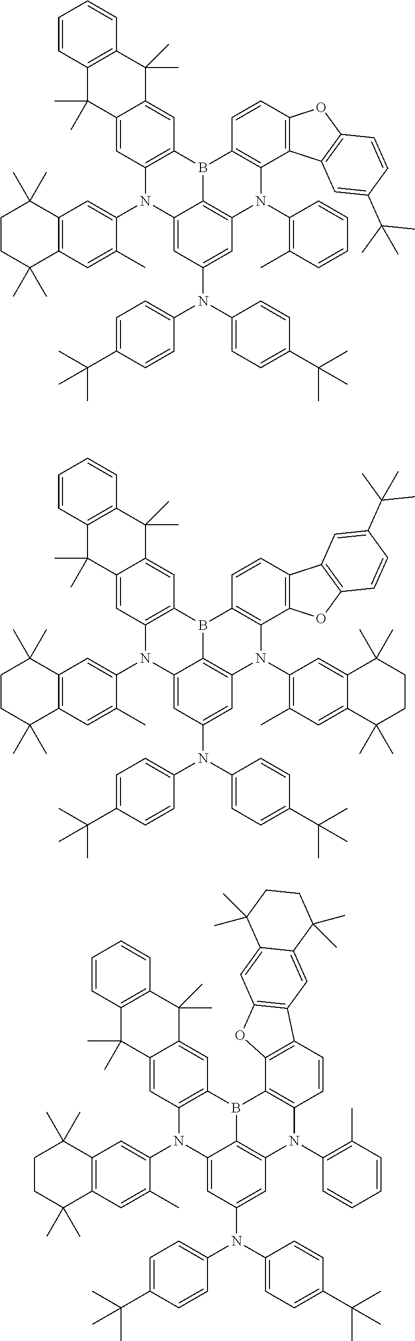

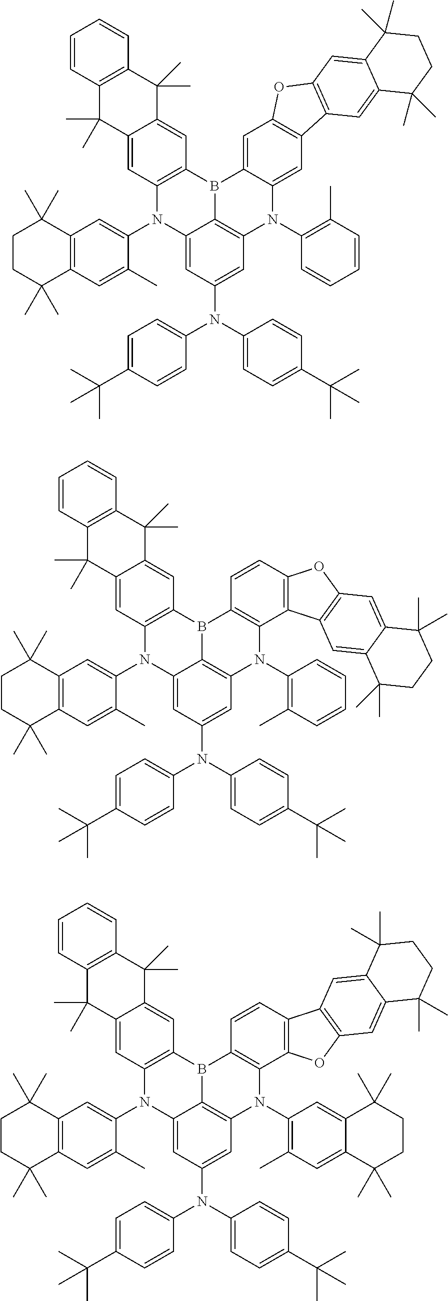

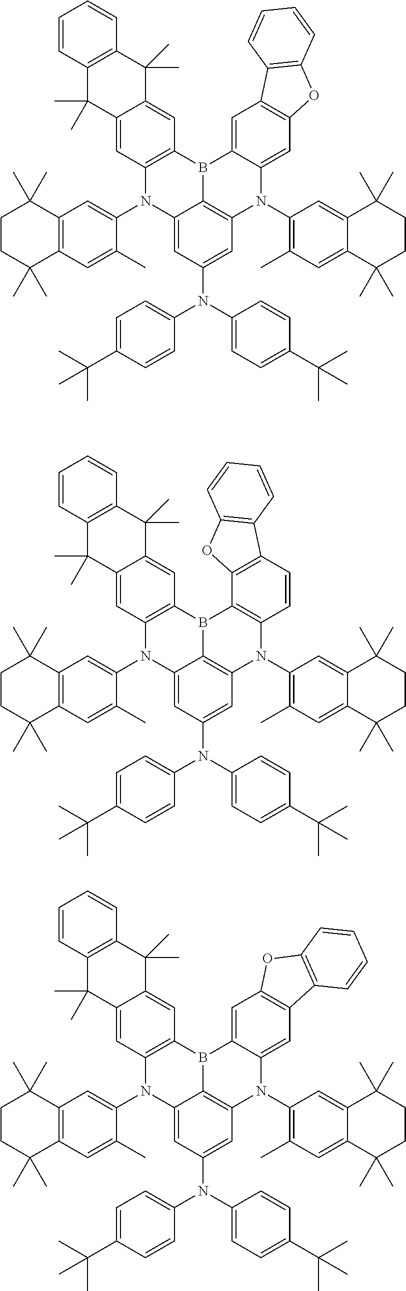

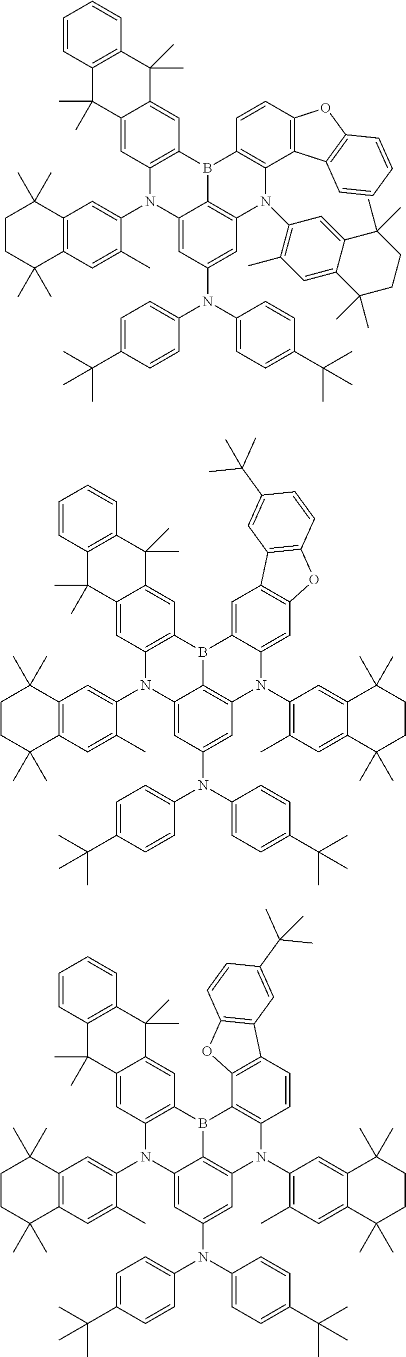

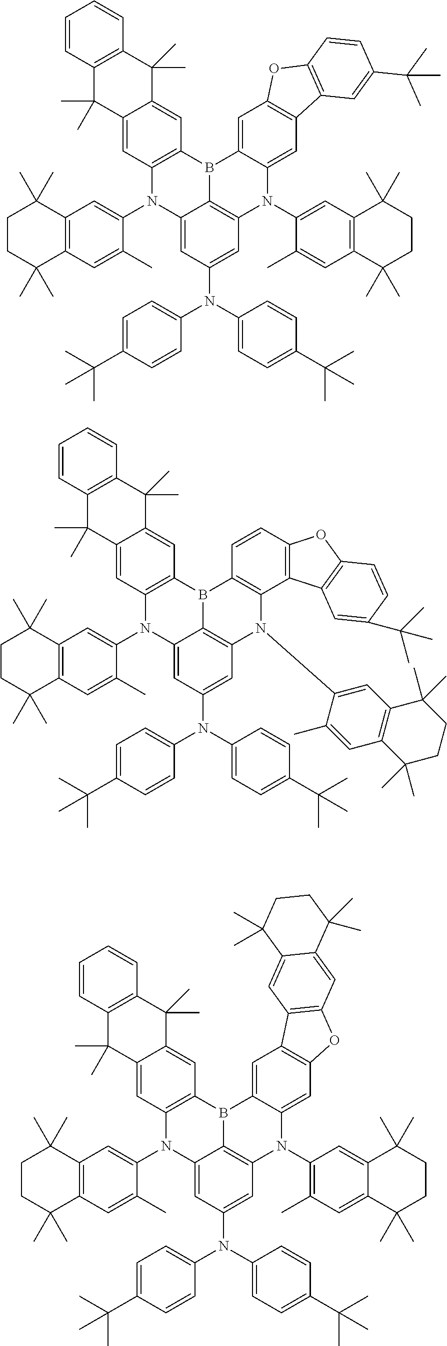

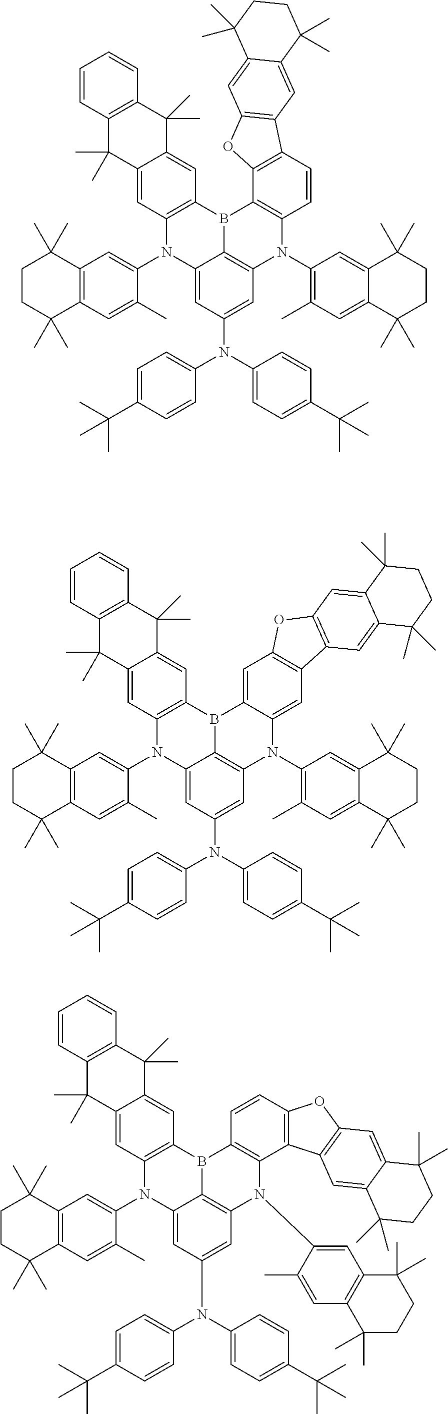

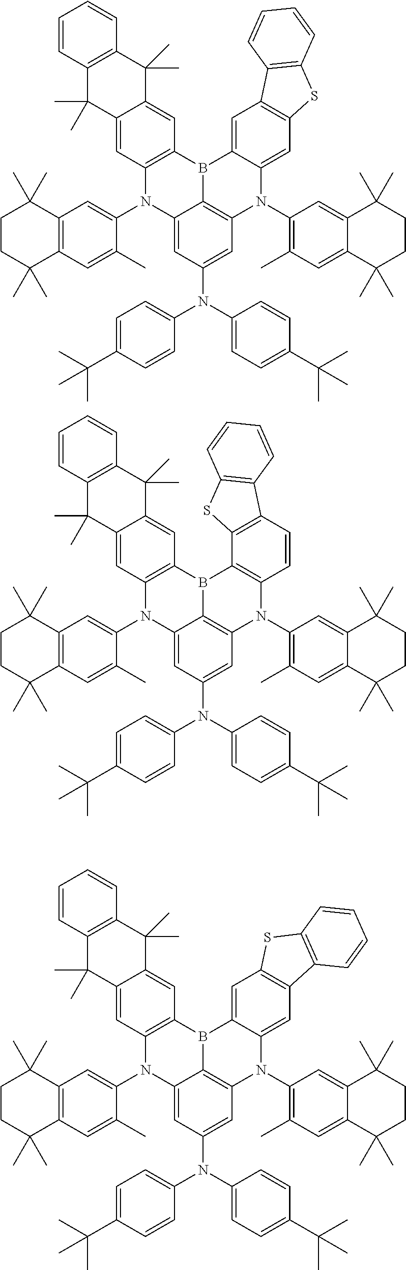

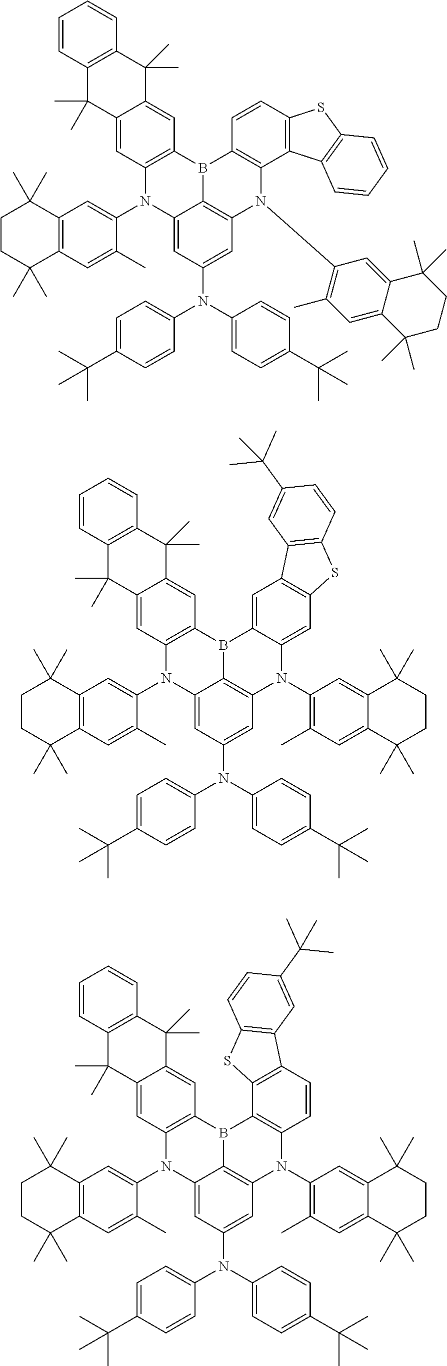

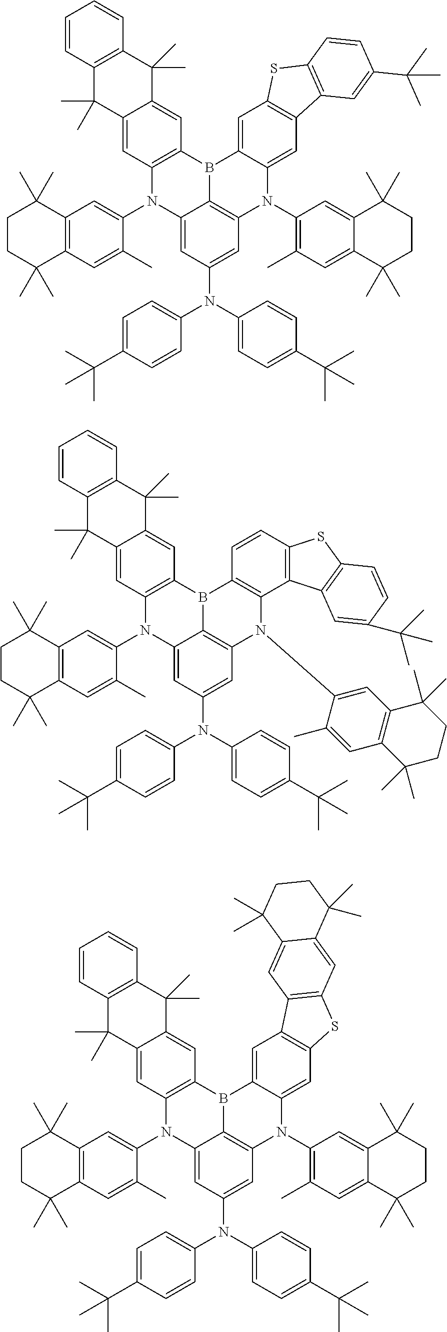

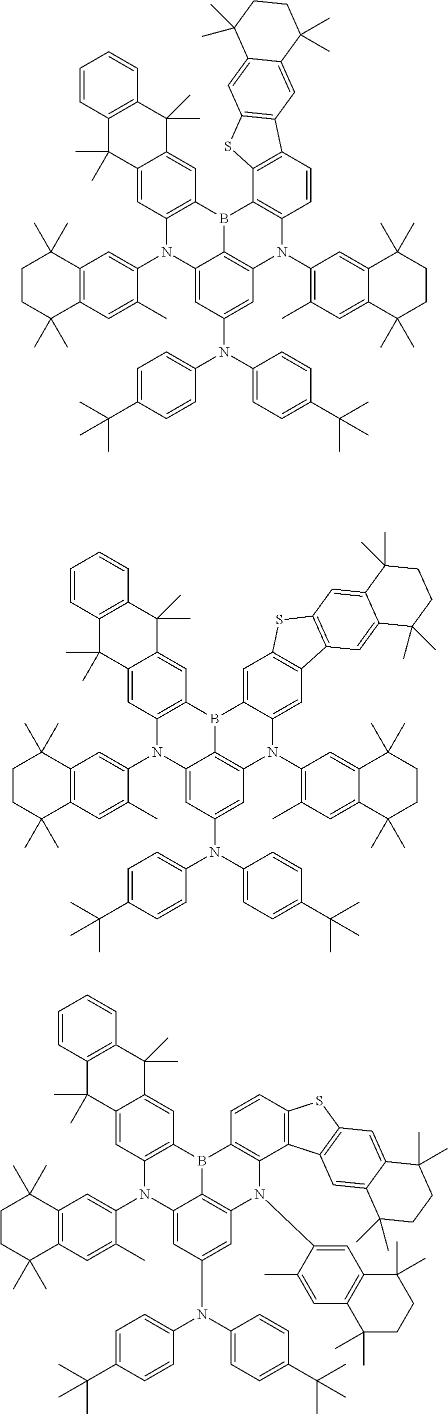

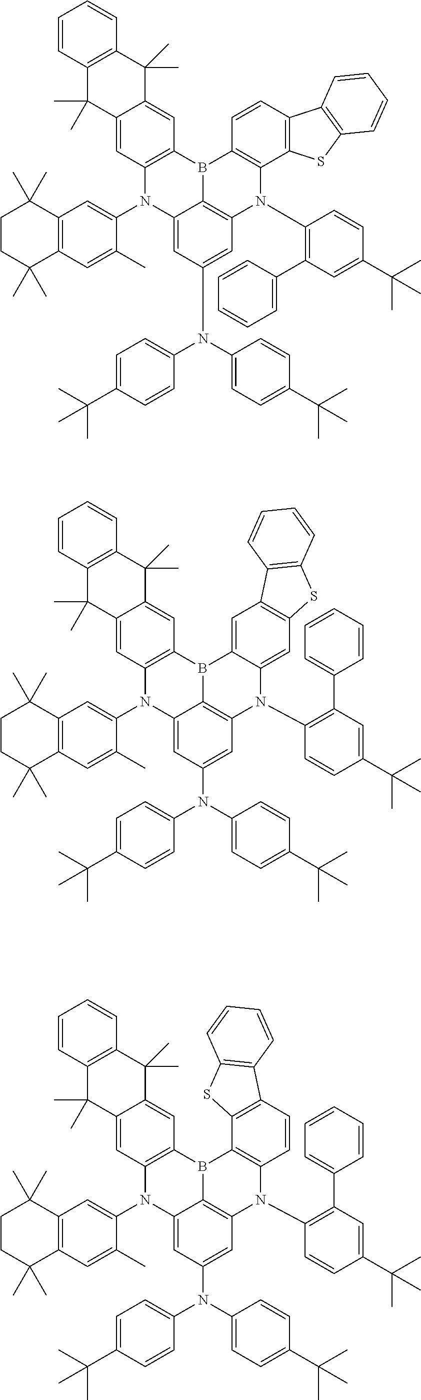

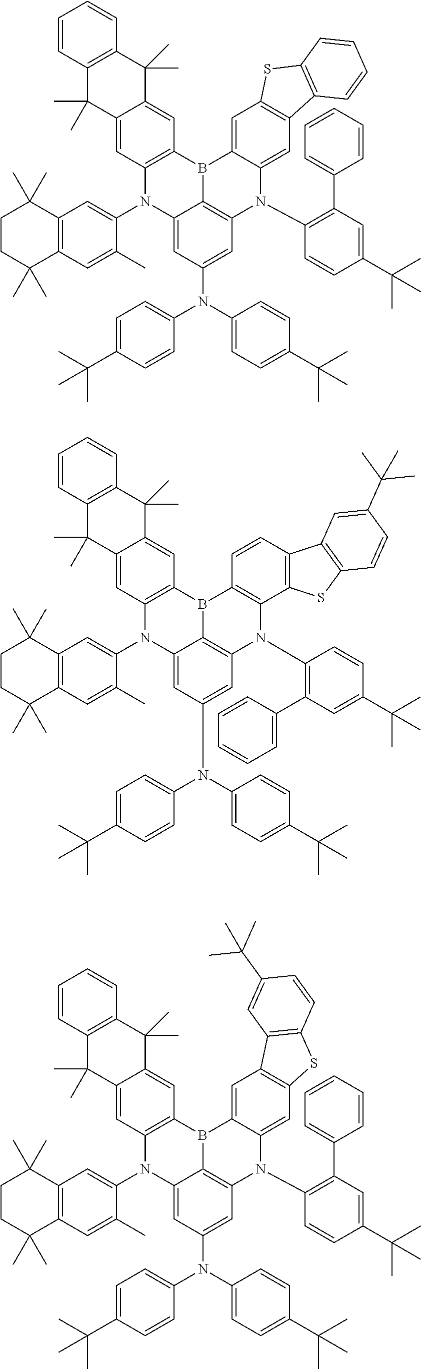

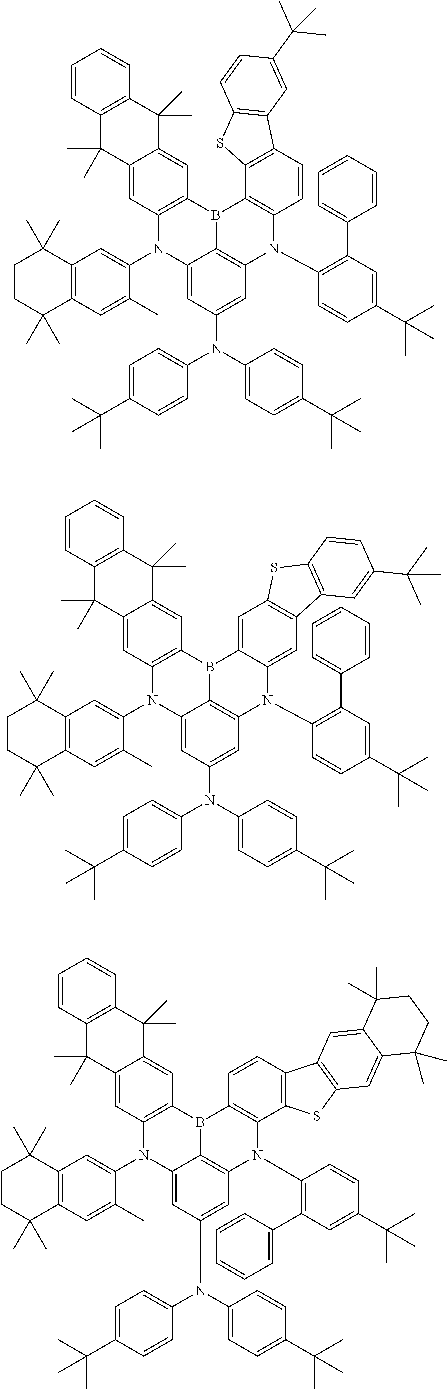

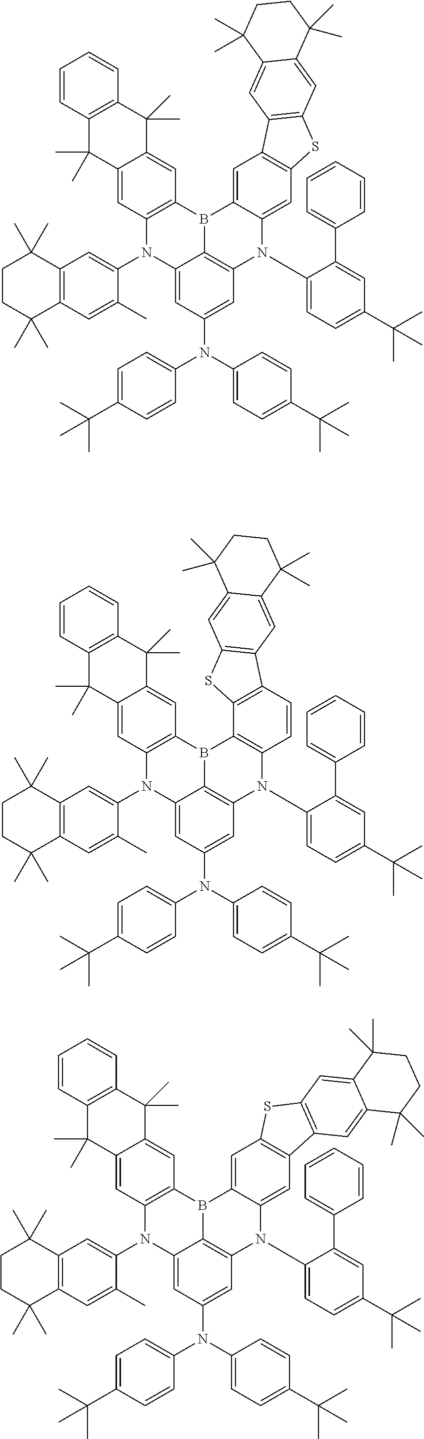

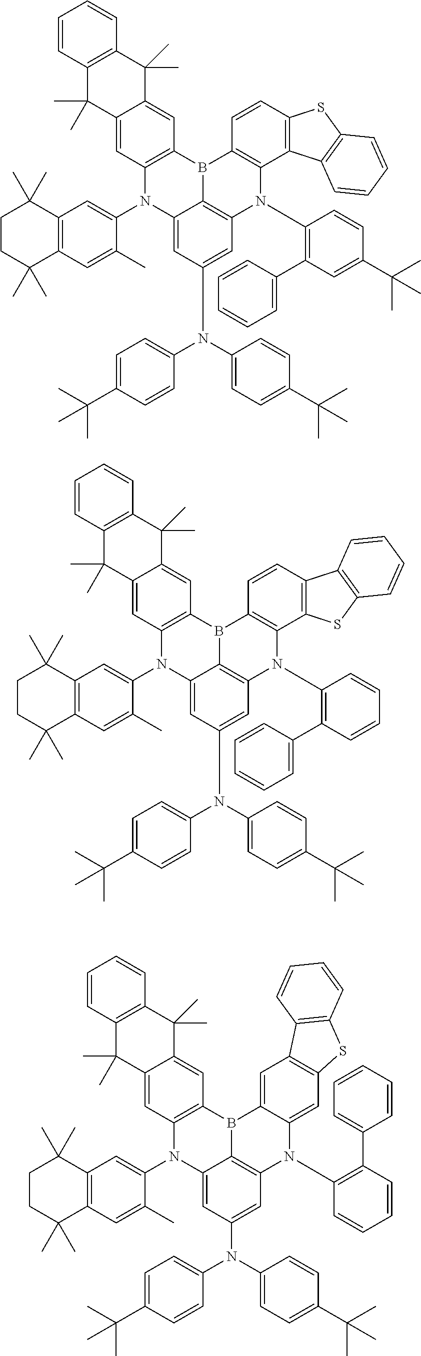

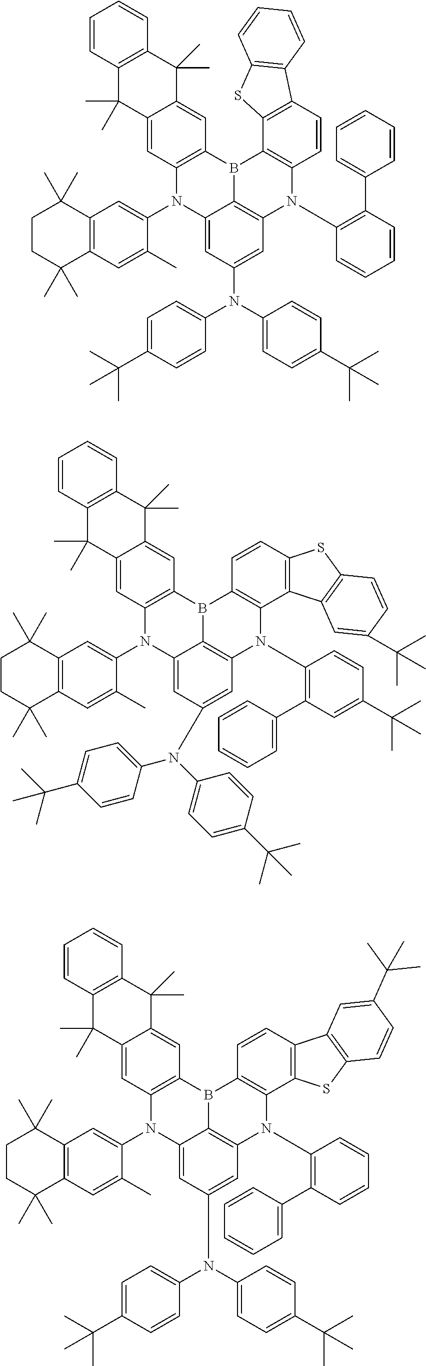 [SMILES: Cc1cc2c(cc1N1c3cc4c(cc3B3c5c1cc(N(c1ccc(C(C)(C)C)cc1)c1ccc(C(C)(C)C)cc1)cc5N(c1ccccc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

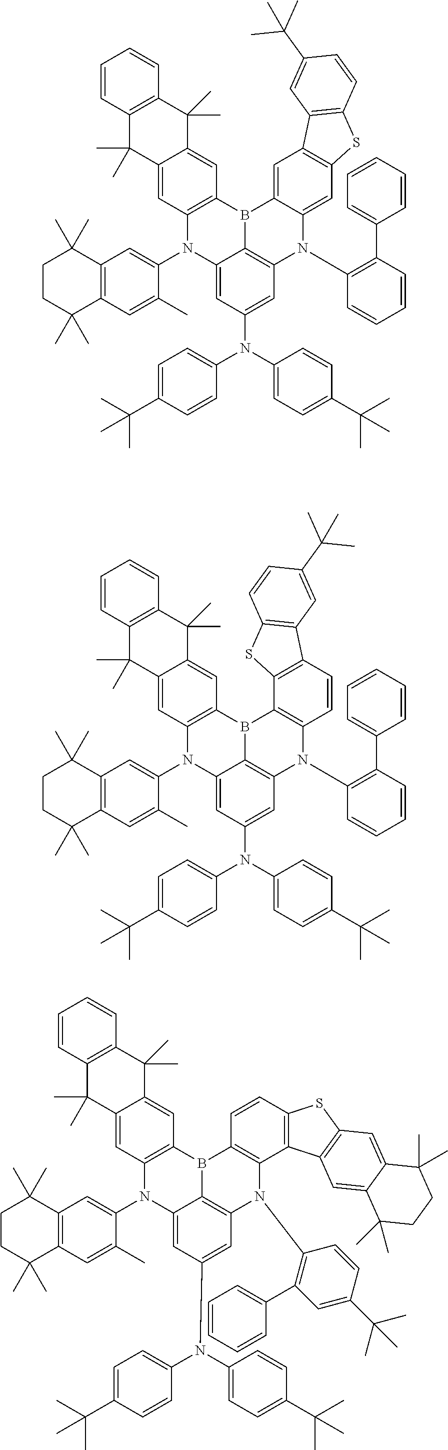

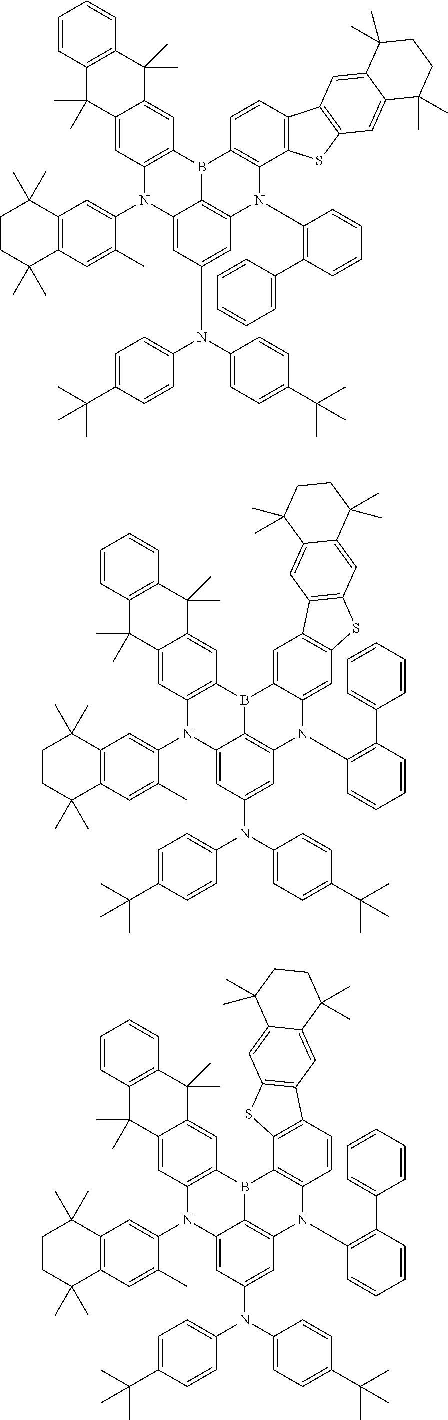

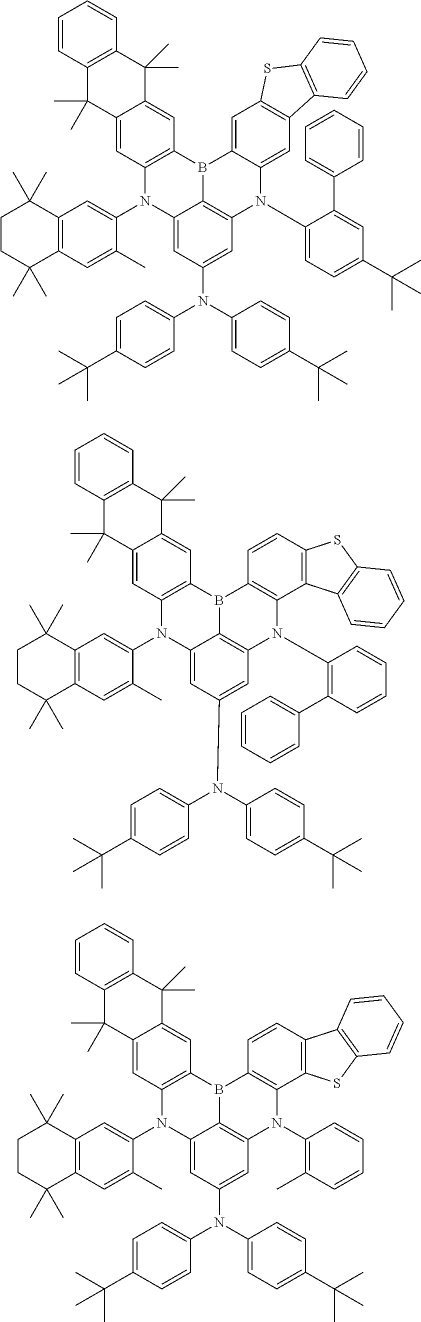

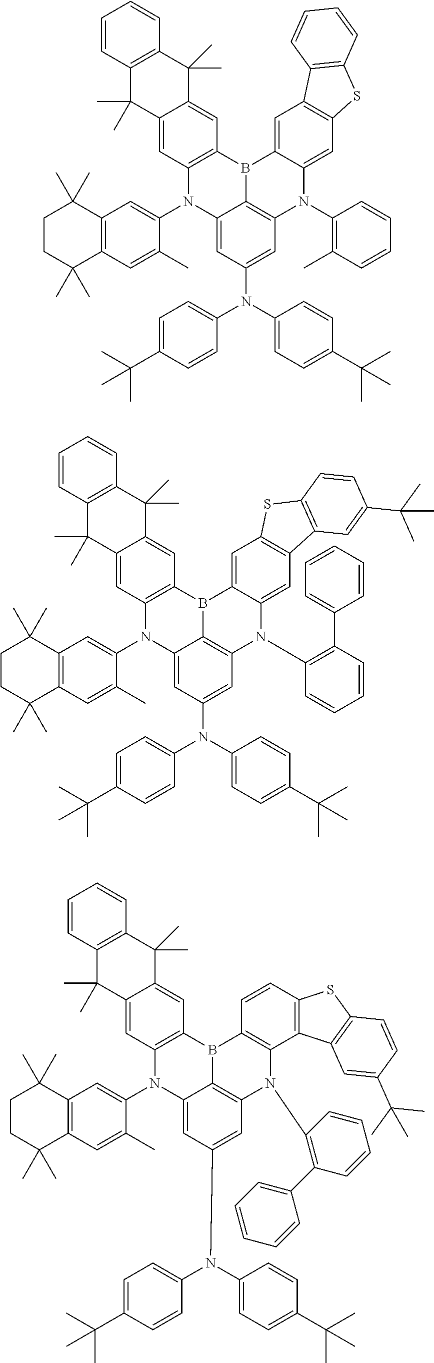 [SMILES: Cc1ccccc1N1c2cc3sc4ccccc4c3cc2B2c3cc4c(cc3N(c3cc5c(cc3C)C(C)(C)CCC5(C)C)c3cc(N(c5ccc(C(C)(C)C)cc5)c5ccc(C(C)(C)C)cc5)cc1c32)C(C)(C)c1ccccc1C4(C)C ; Cc1cc2c(cc1N1c3cc4c(cc3B3c5cc6sc7ccc(C(C)(C)C)cc7c6cc5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

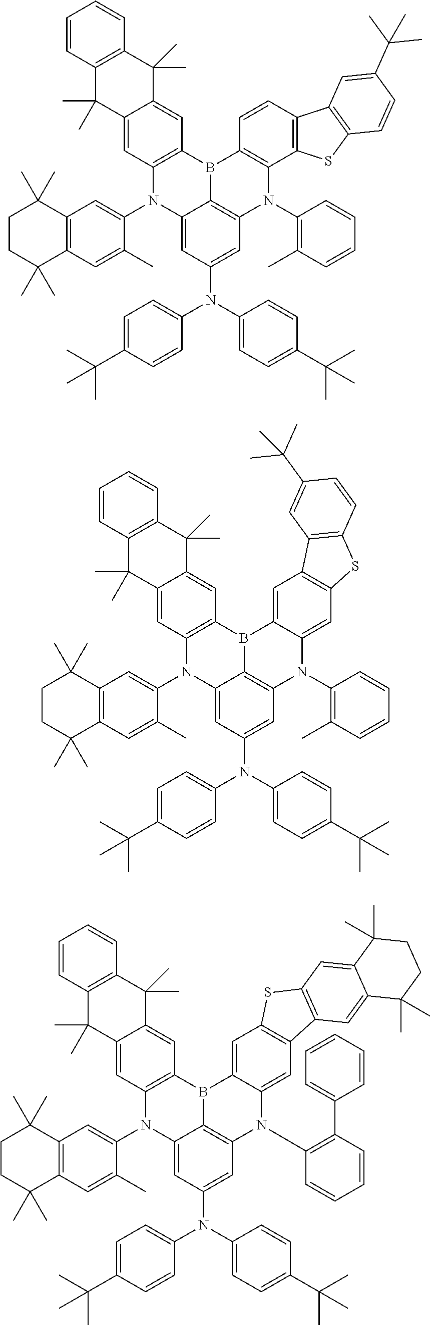

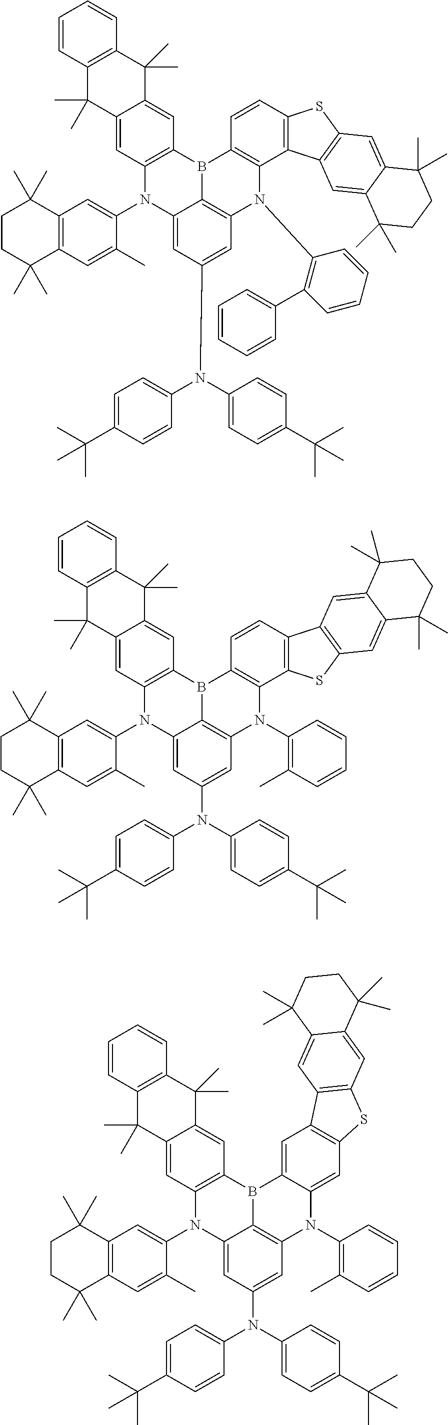

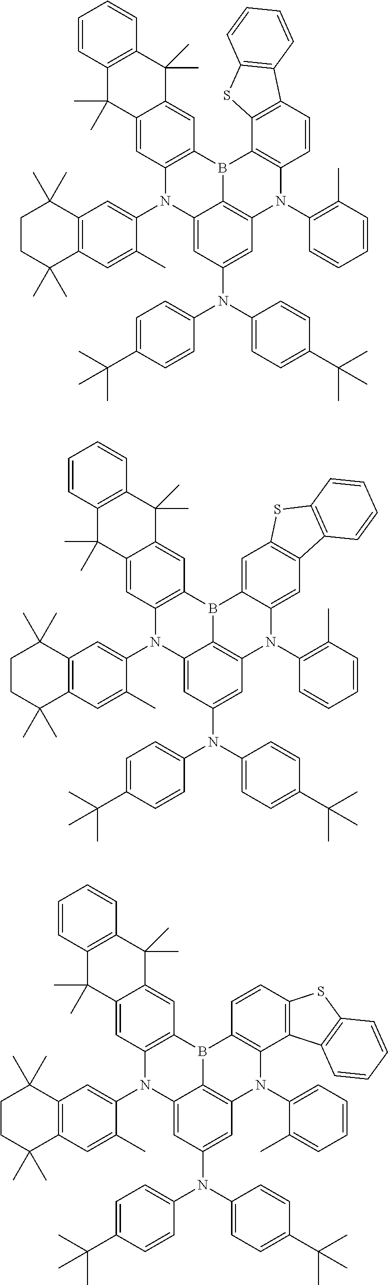

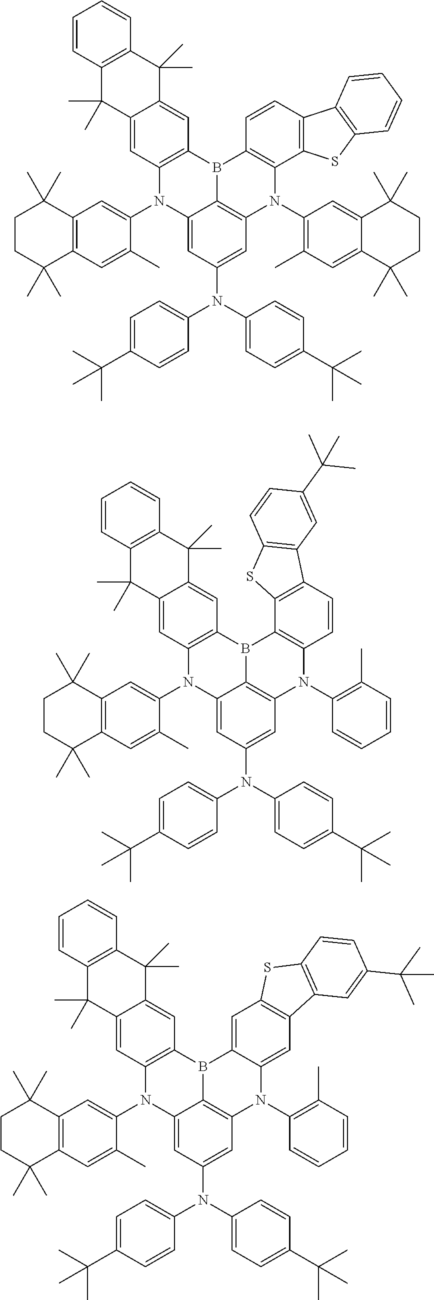

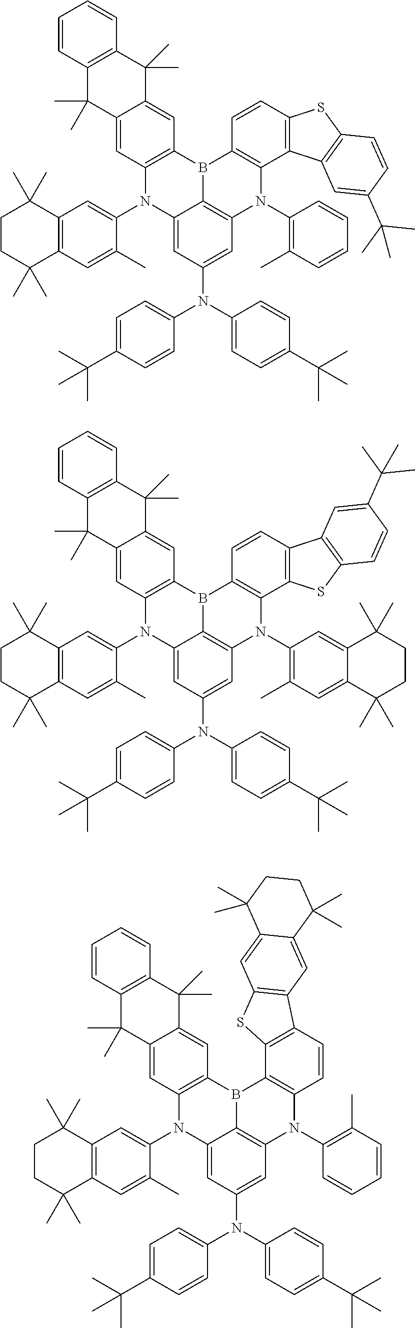

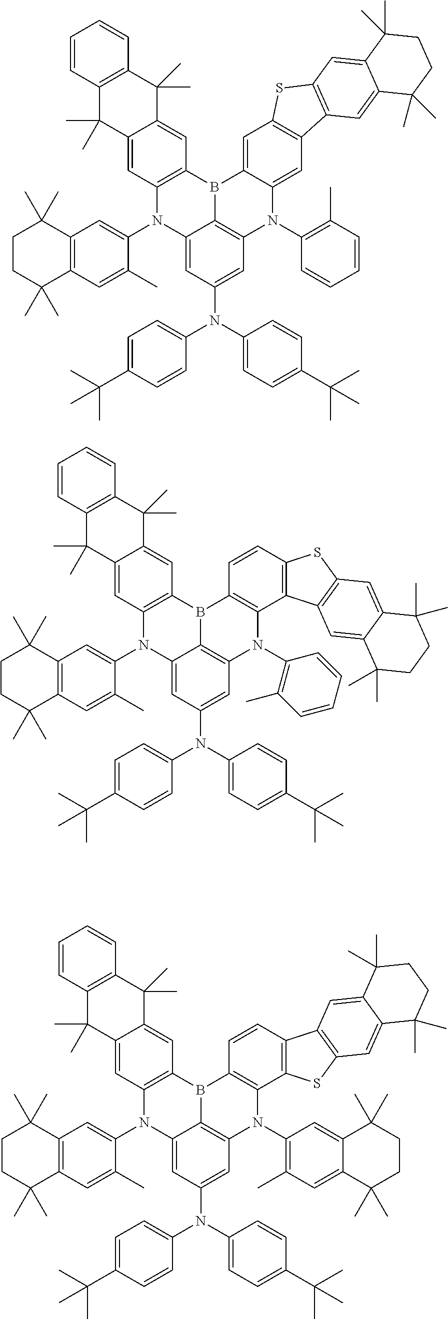

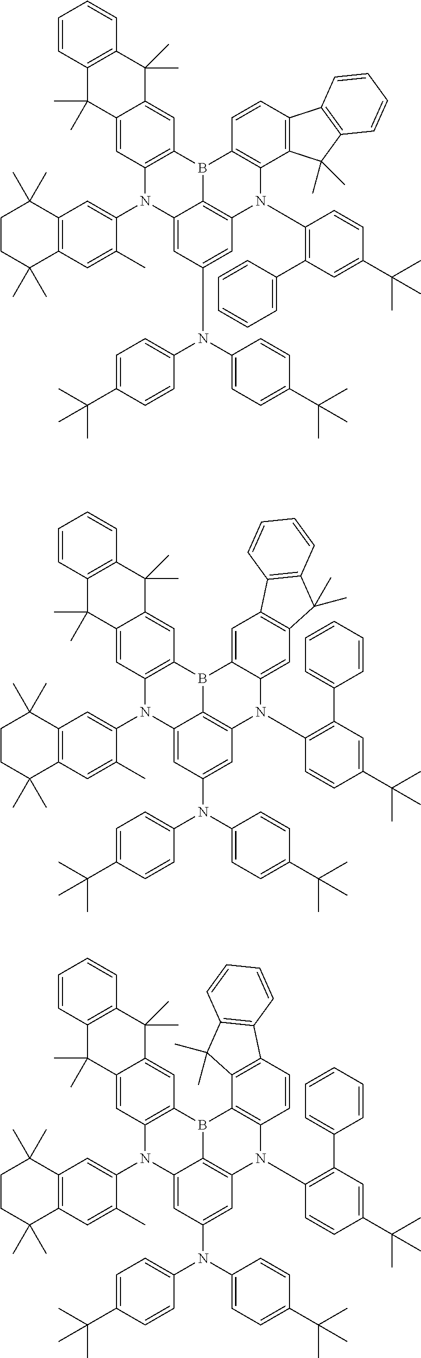

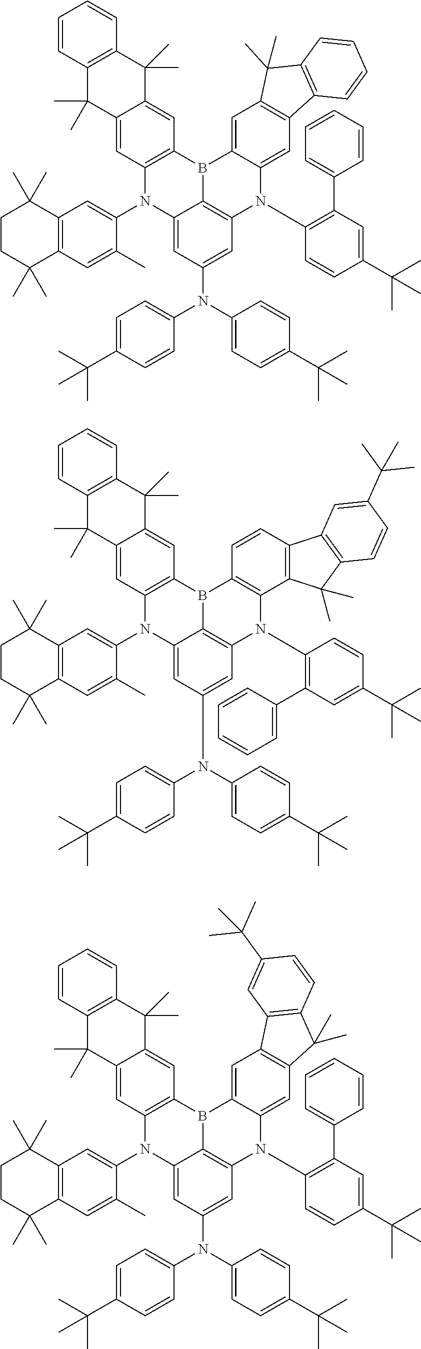

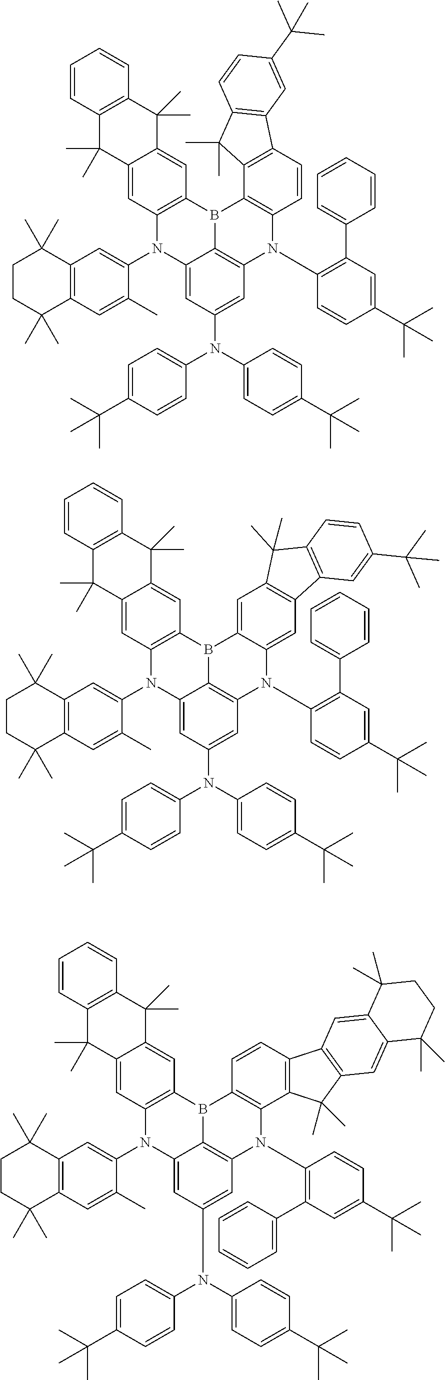

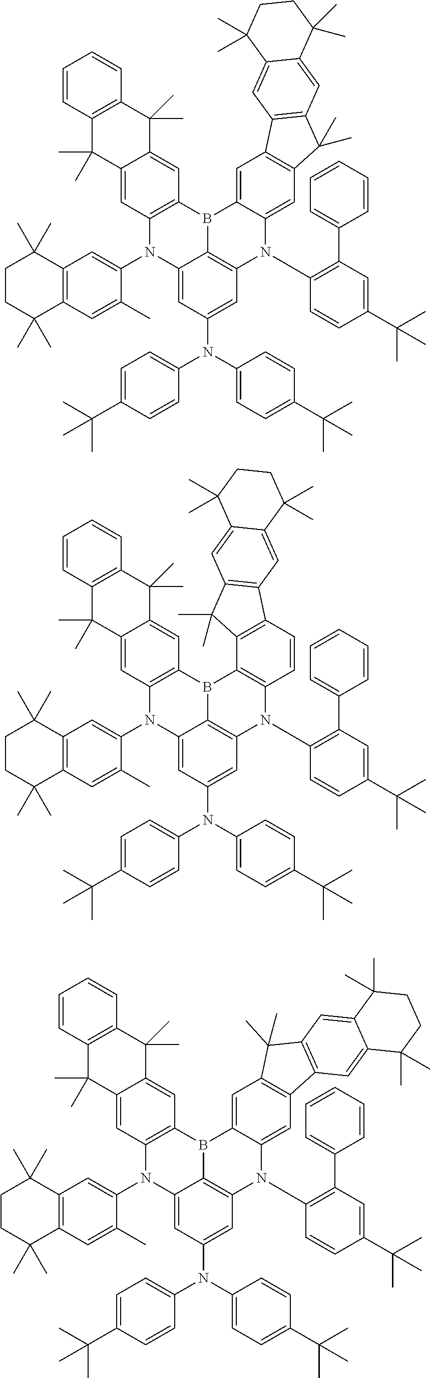

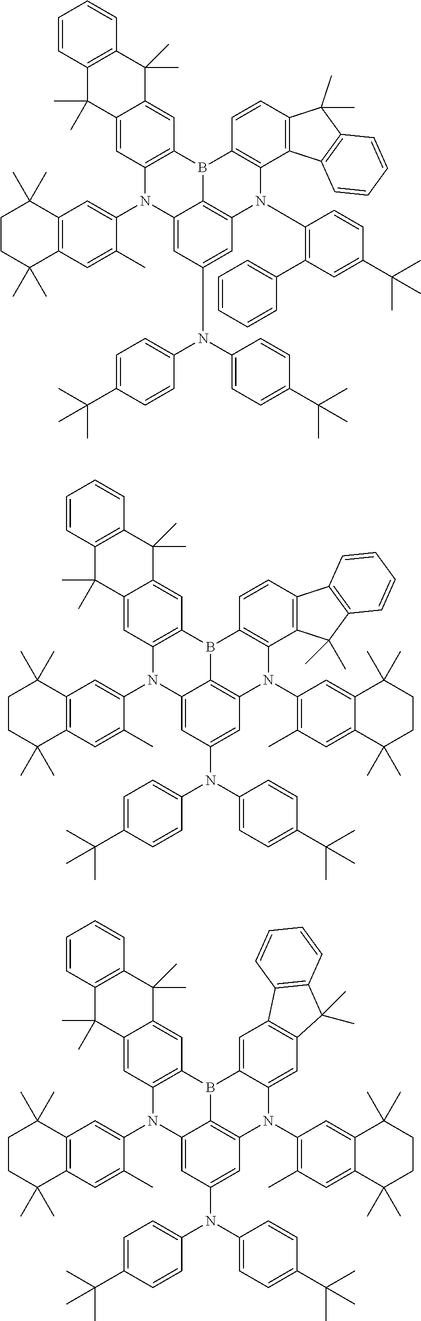

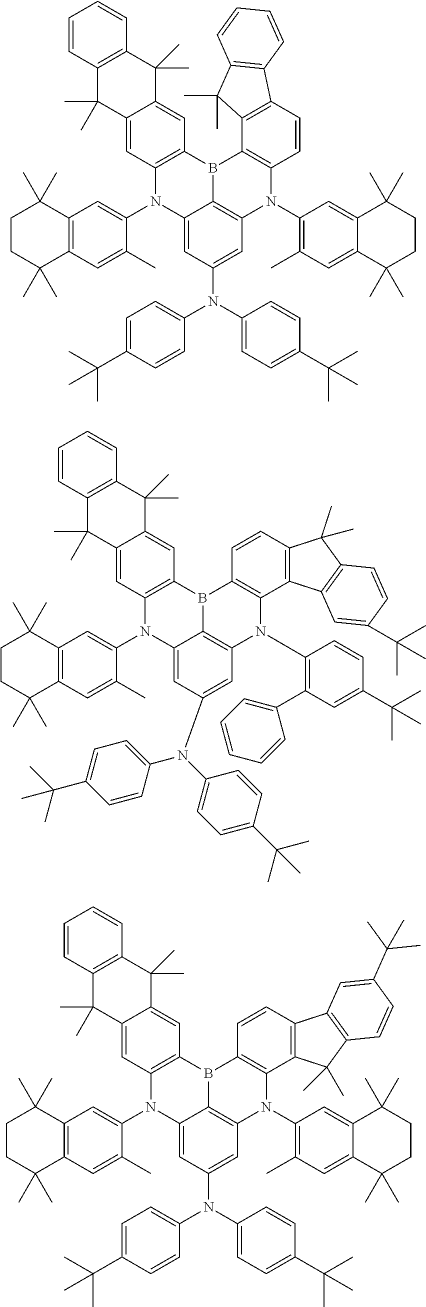

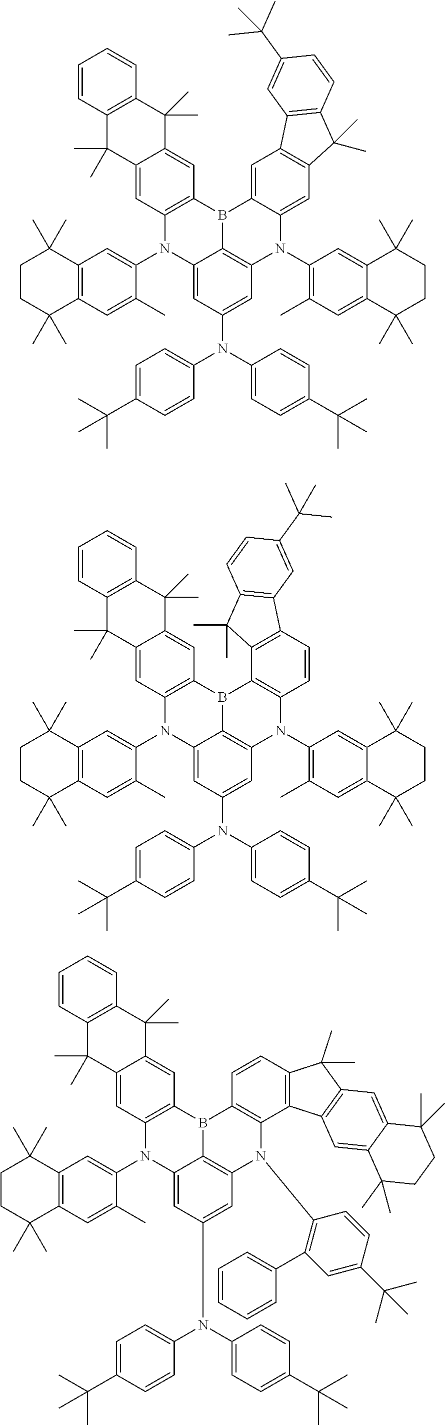

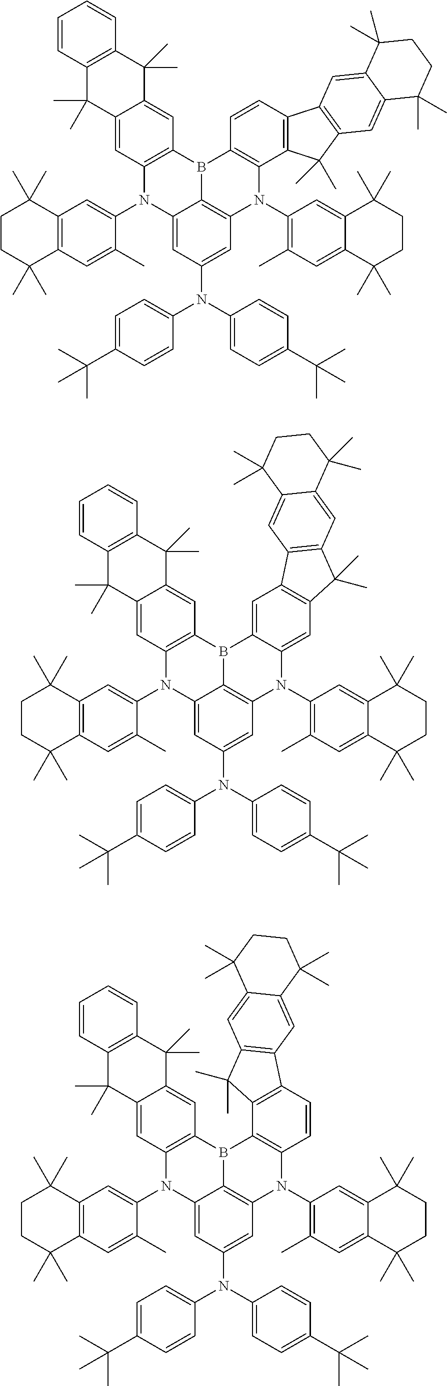

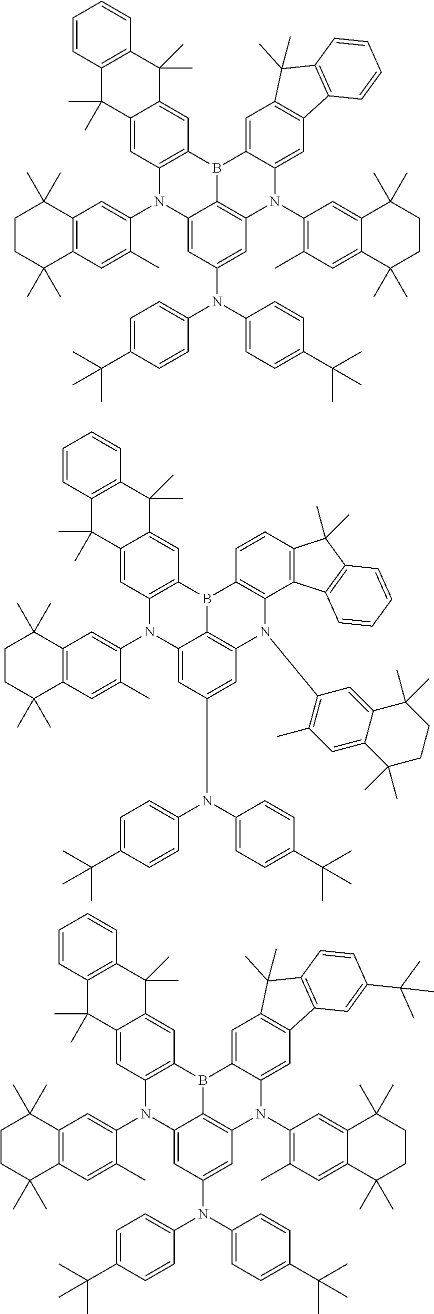

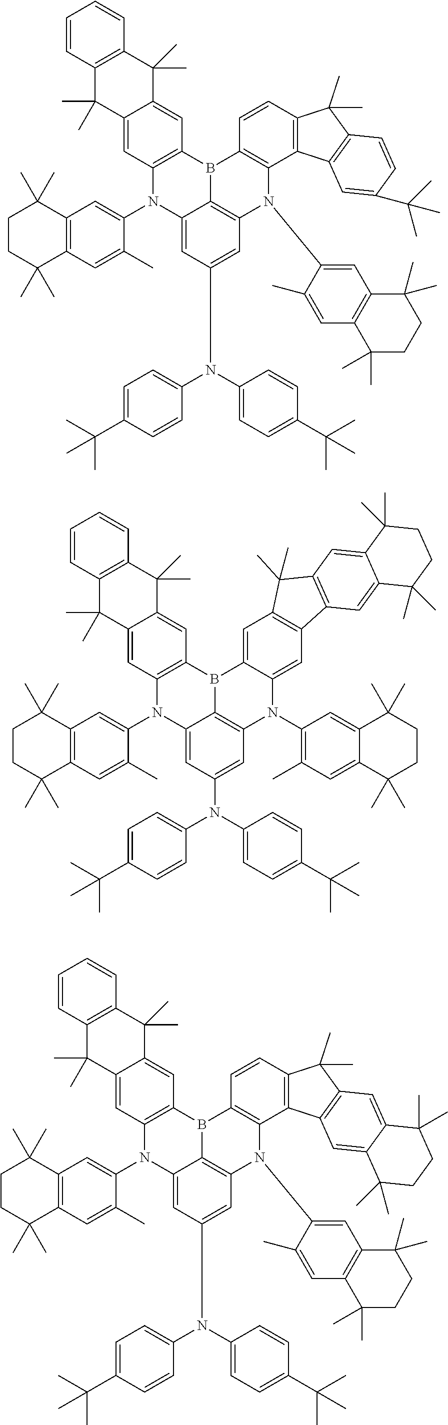

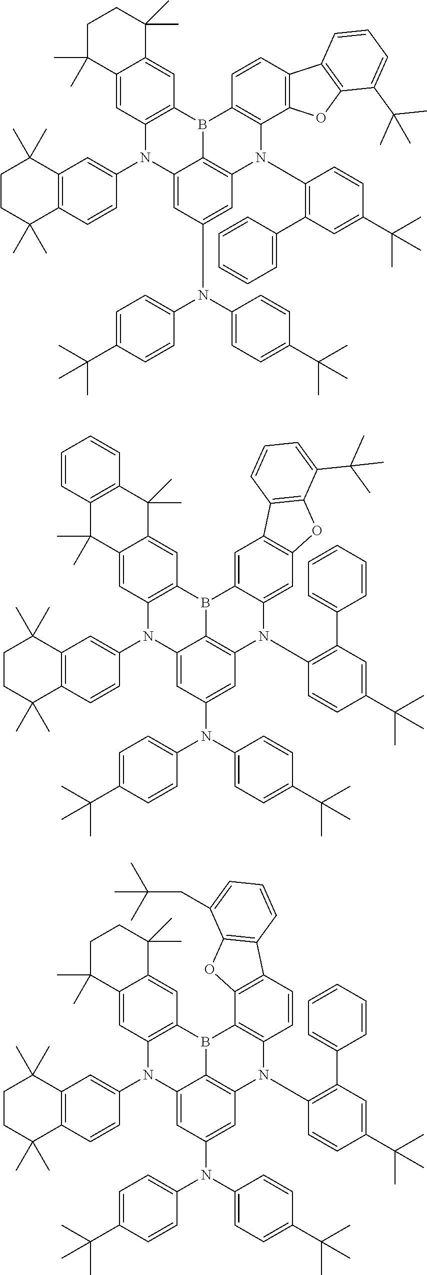

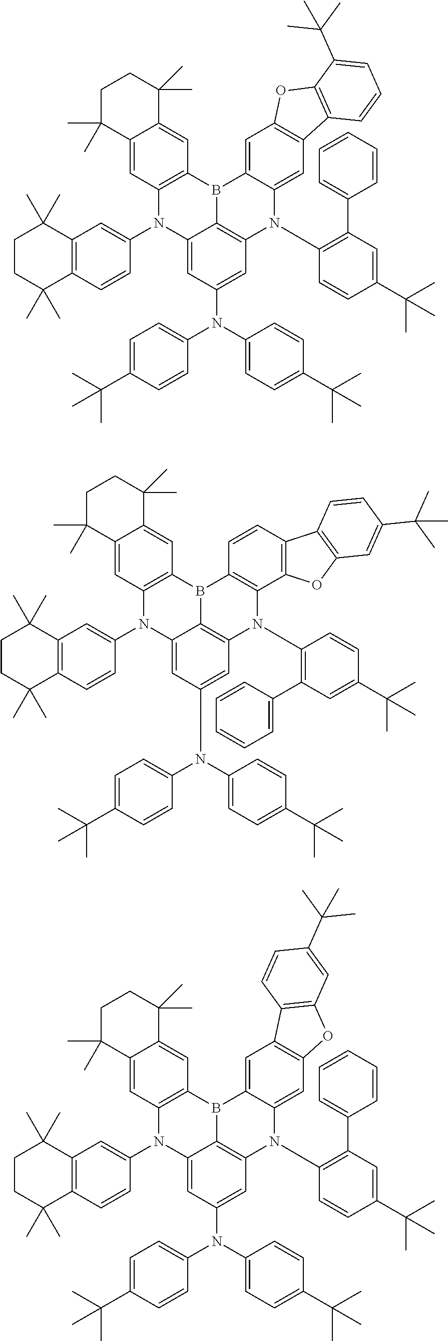

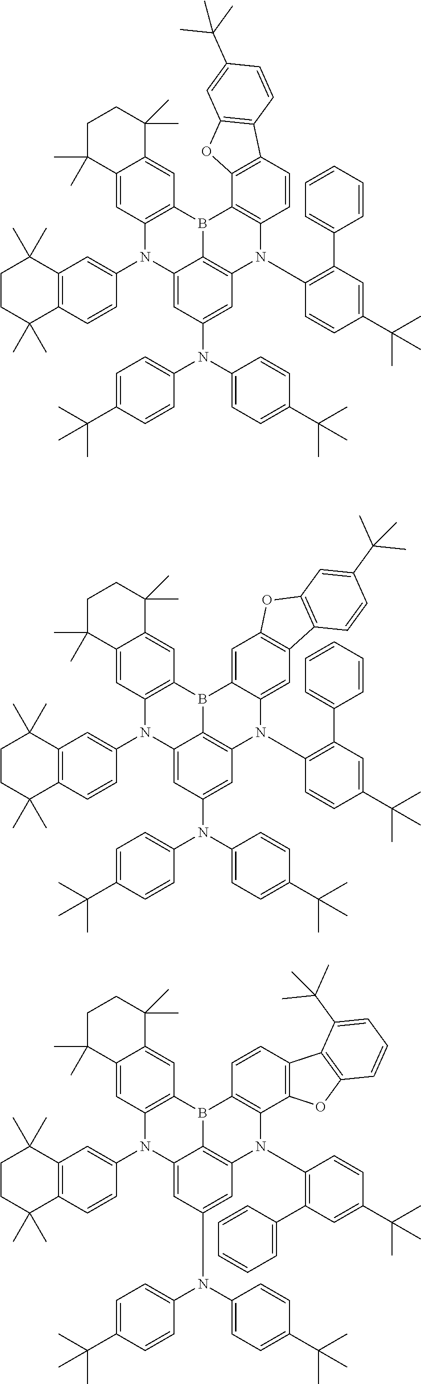

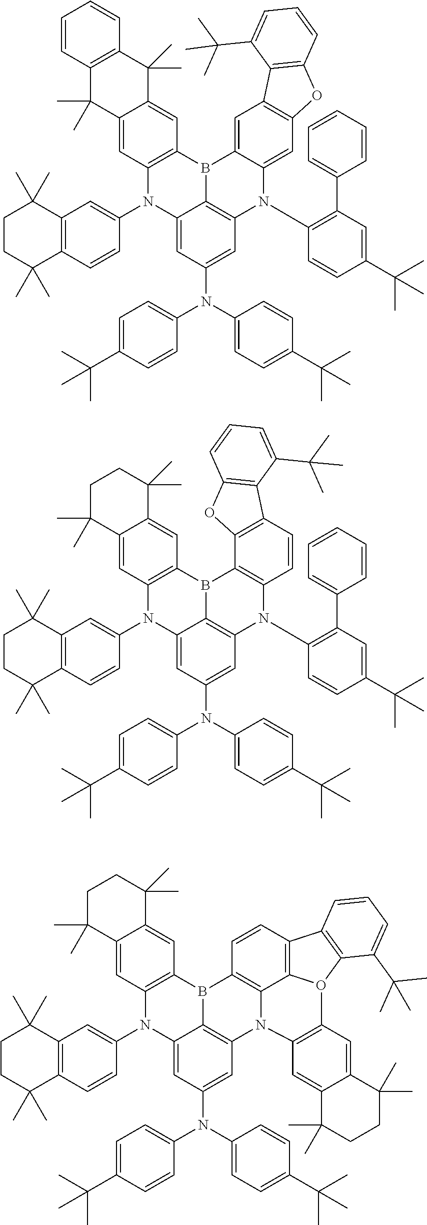

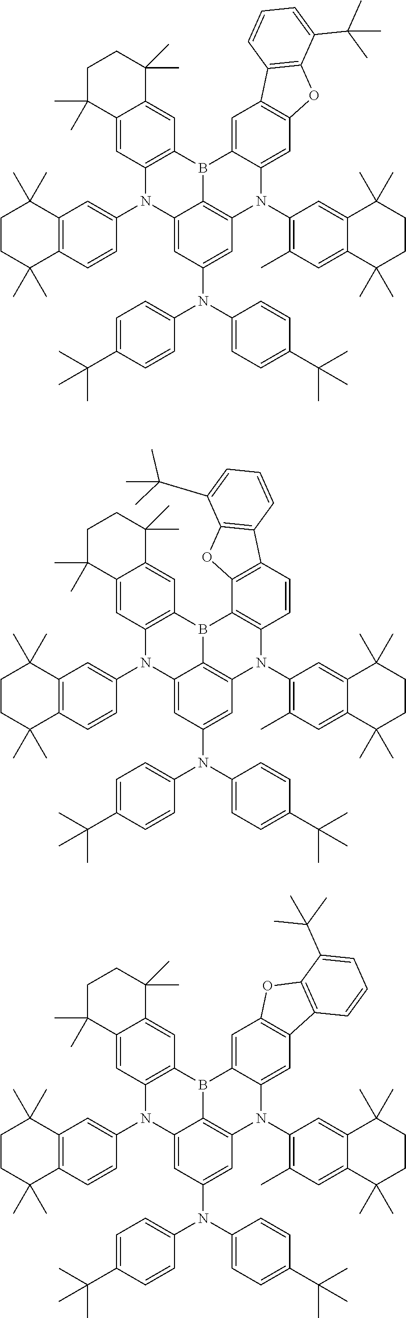

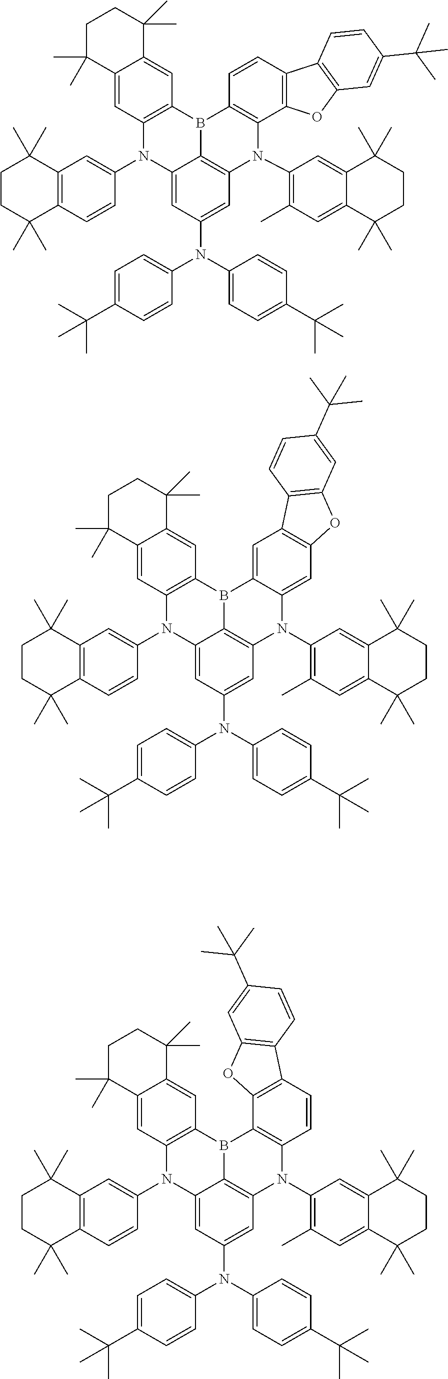

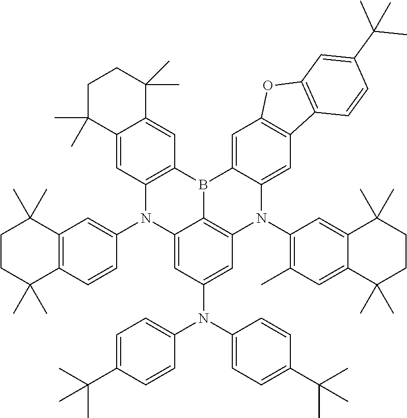 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)oc1cc(C(C)(C)C)ccc14)C(C)(C)CCC2(C)C]

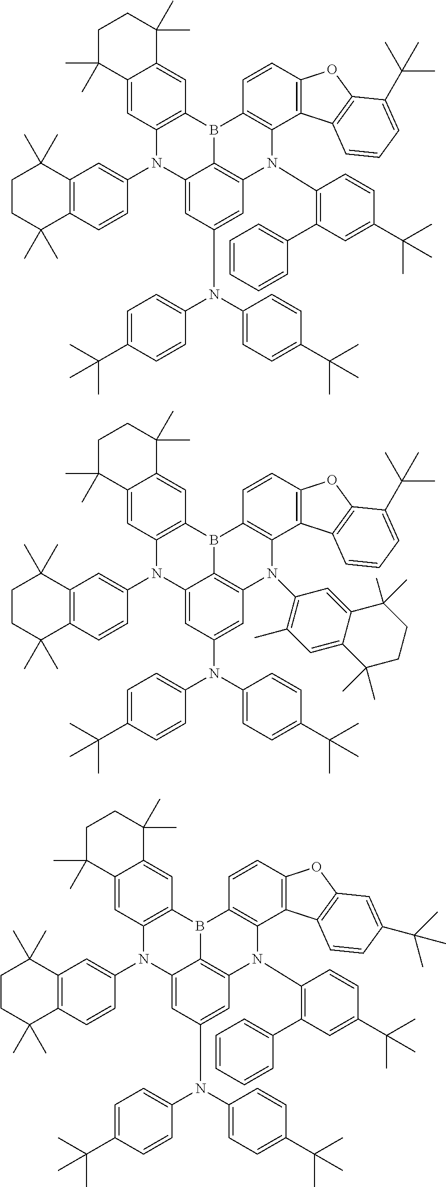

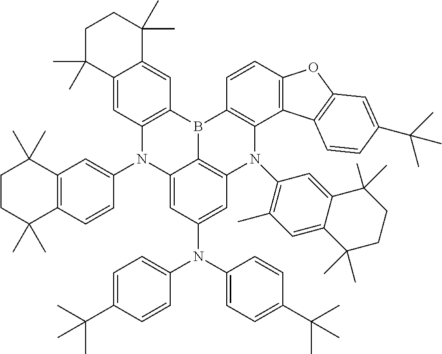 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4oc5cc(C(C)(C)C)ccc5c4c31)C(C)(C)CCC2(C)C]

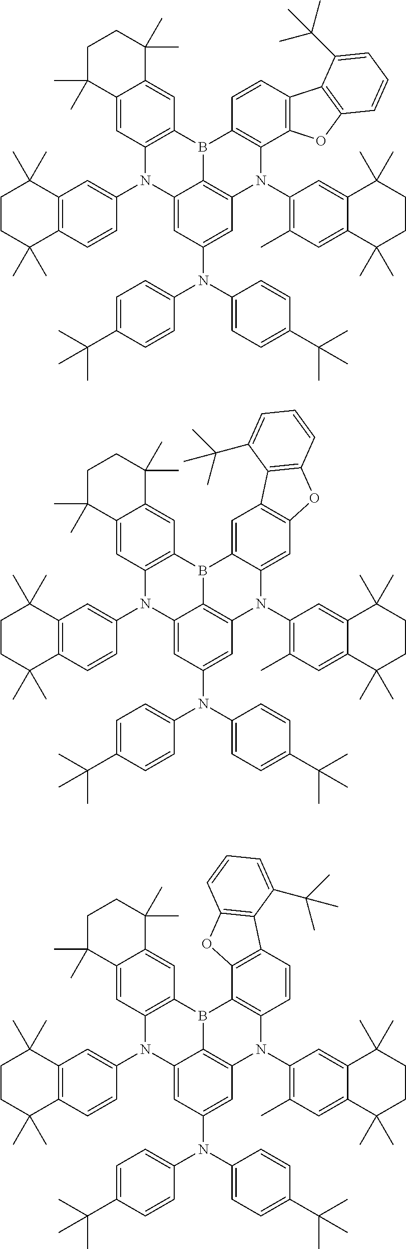

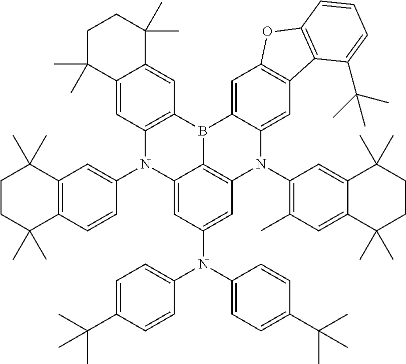 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)oc1cccc(C(C)(C)C)c14)C(C)(C)CCC2(C)C]

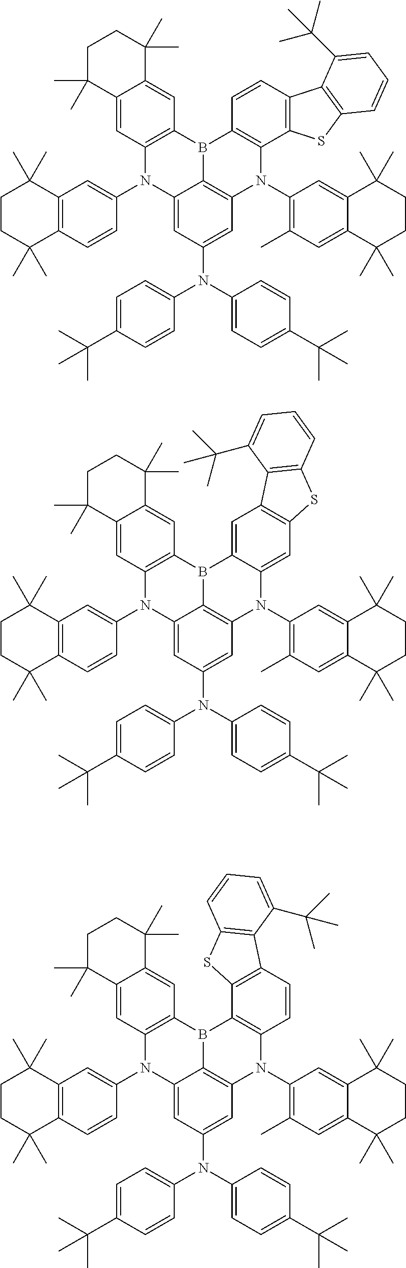

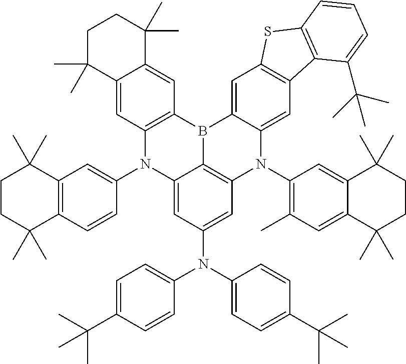 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)sc1cccc(C(C)(C)C)c14)C(C)(C)CCC2(C)C]

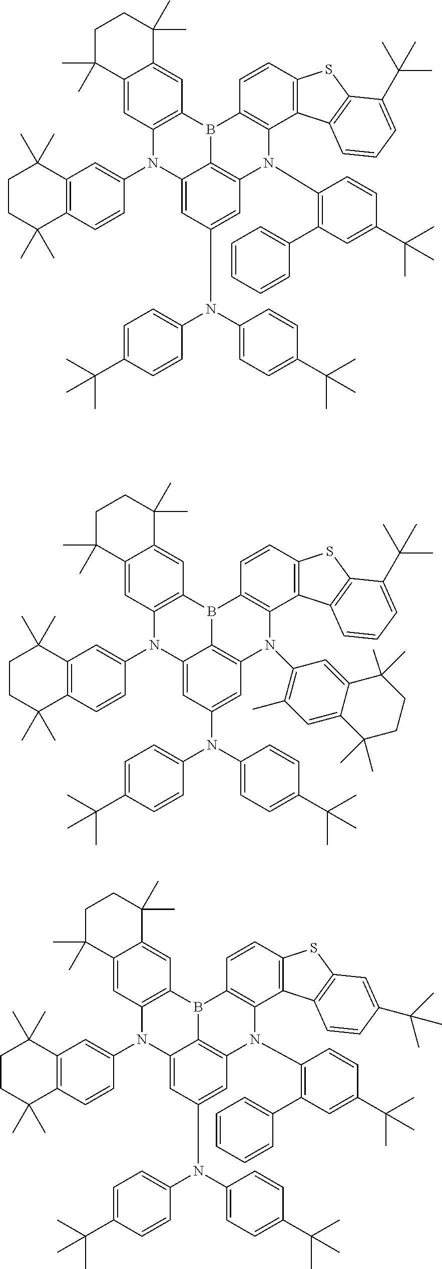

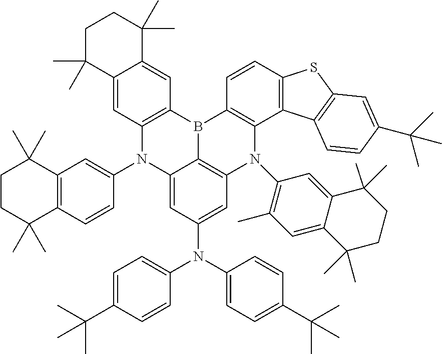 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4sc5cc(C(C)(C)C)ccc5c4c31)C(C)(C)CCC2(C)C]

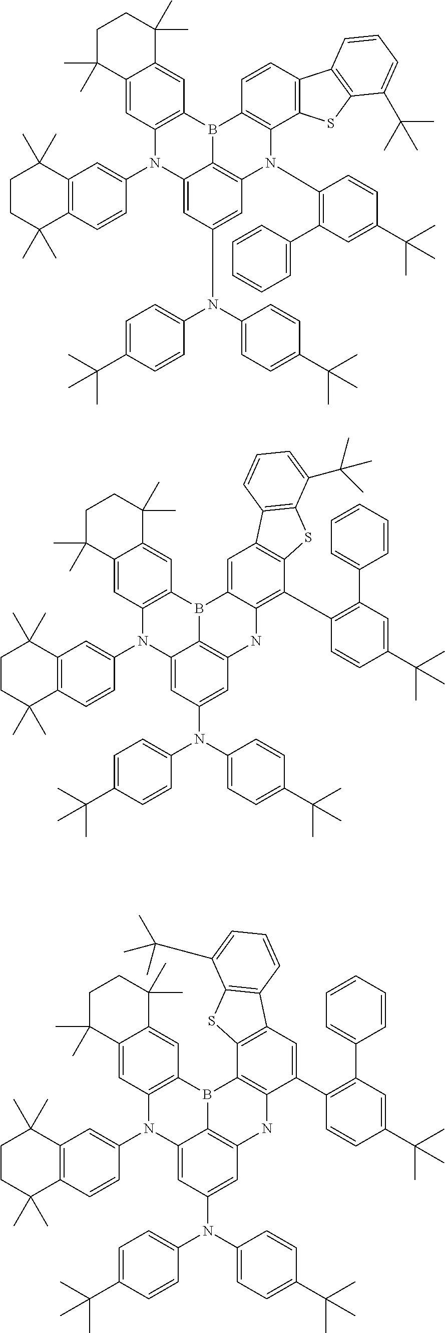

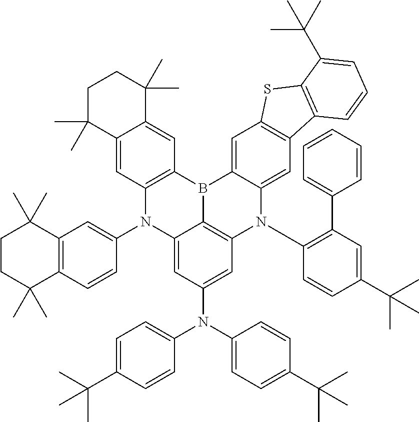 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2c(C(C)(C)C)cccc25)cc1]

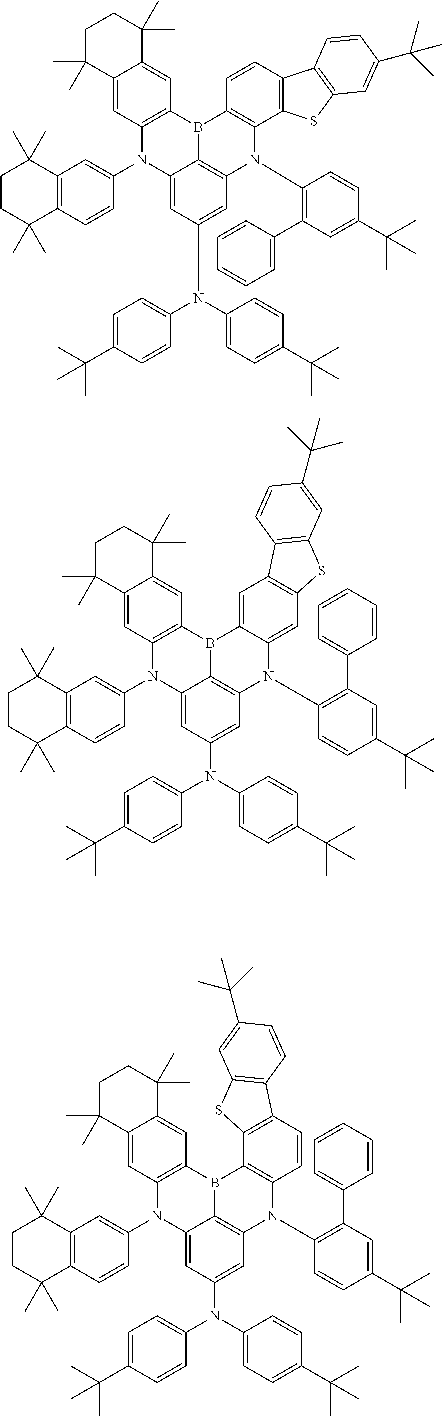

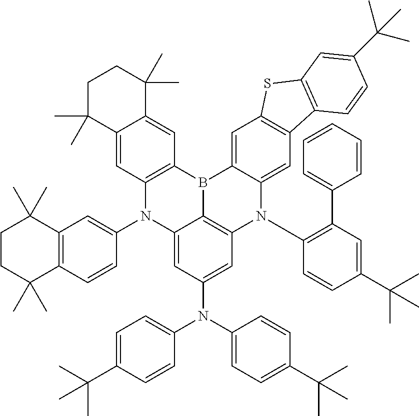 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2cc(C(C)(C)C)ccc25)cc1]

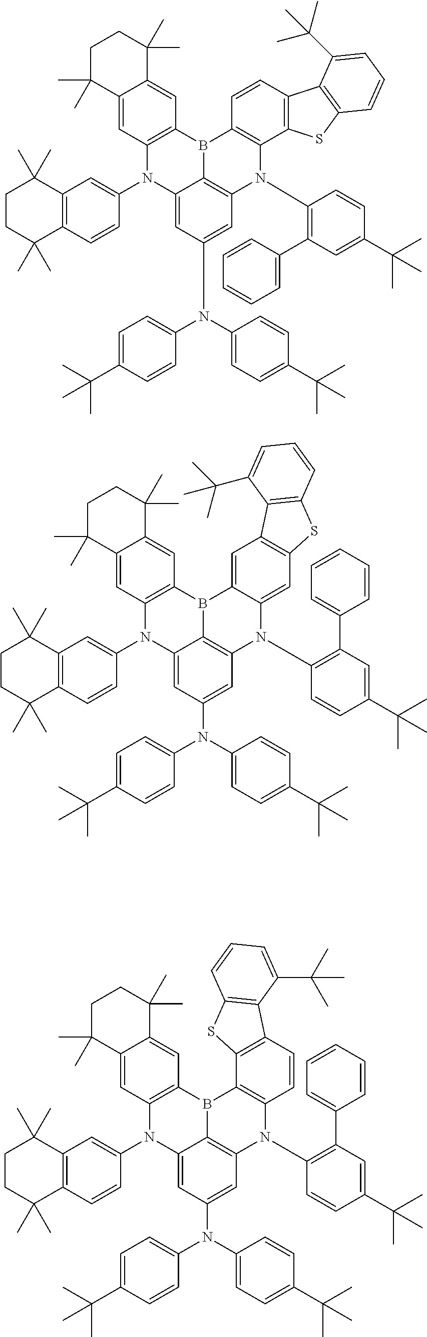

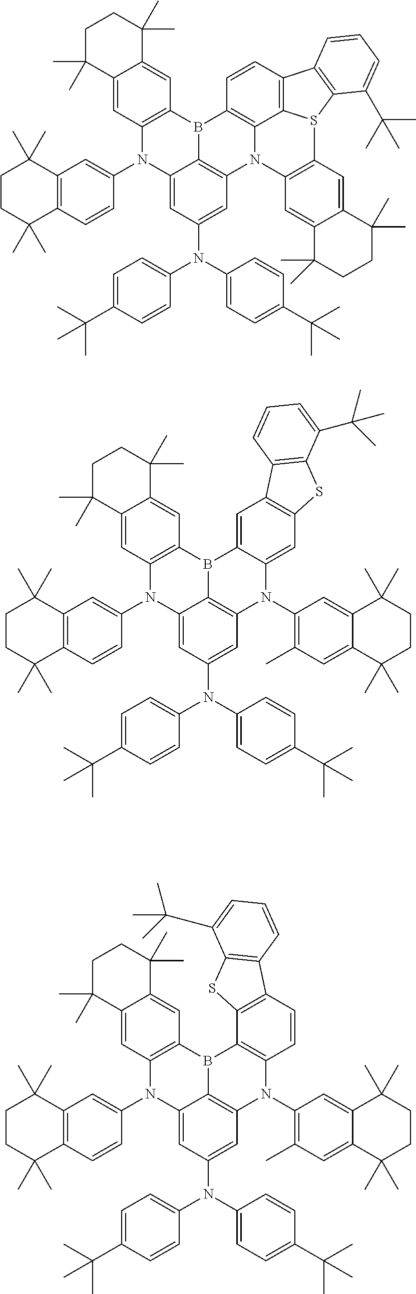

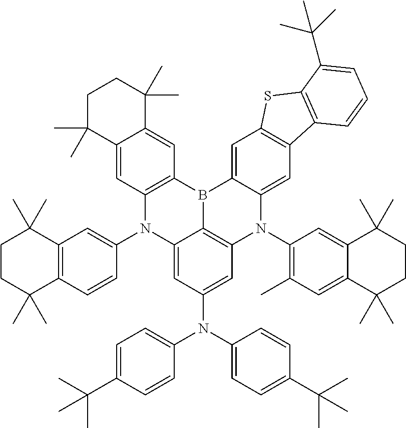 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)sc1c(C(C)(C)C)cccc14)C(C)(C)CCC2(C)C]

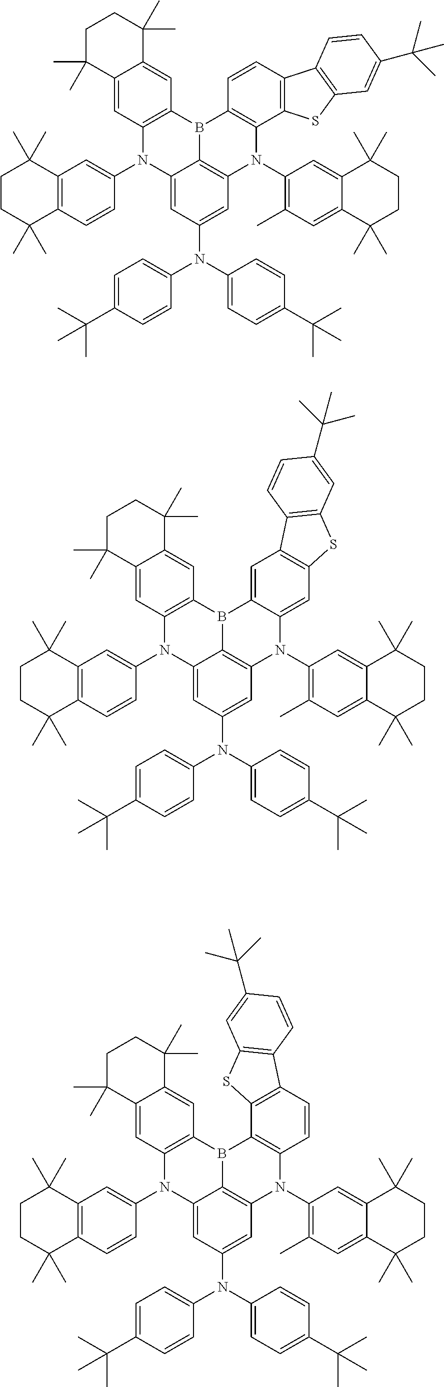

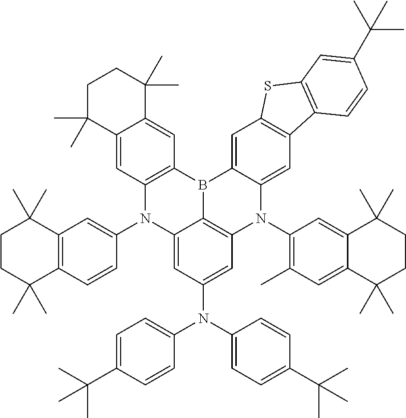 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)sc1cc(C(C)(C)C)ccc14)C(C)(C)CCC2(C)C]

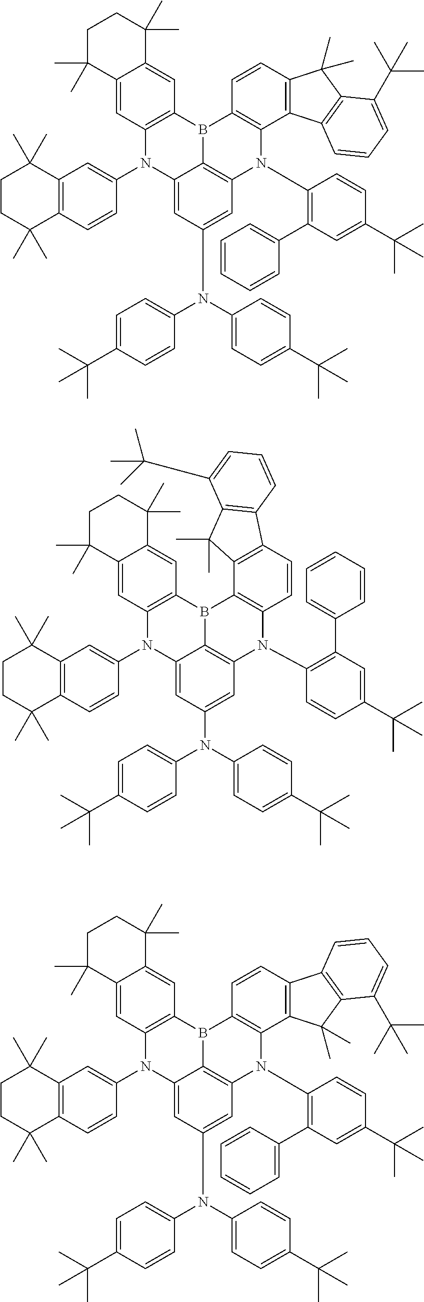

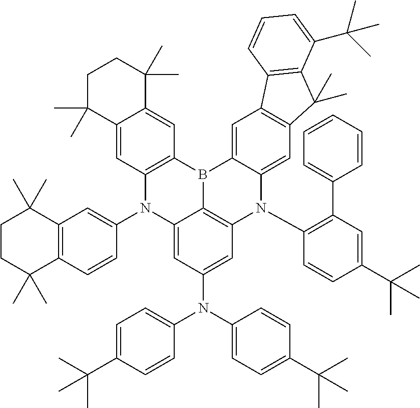 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)-c2cccc(C(C)(C)C)c2C5(C)C)cc1]

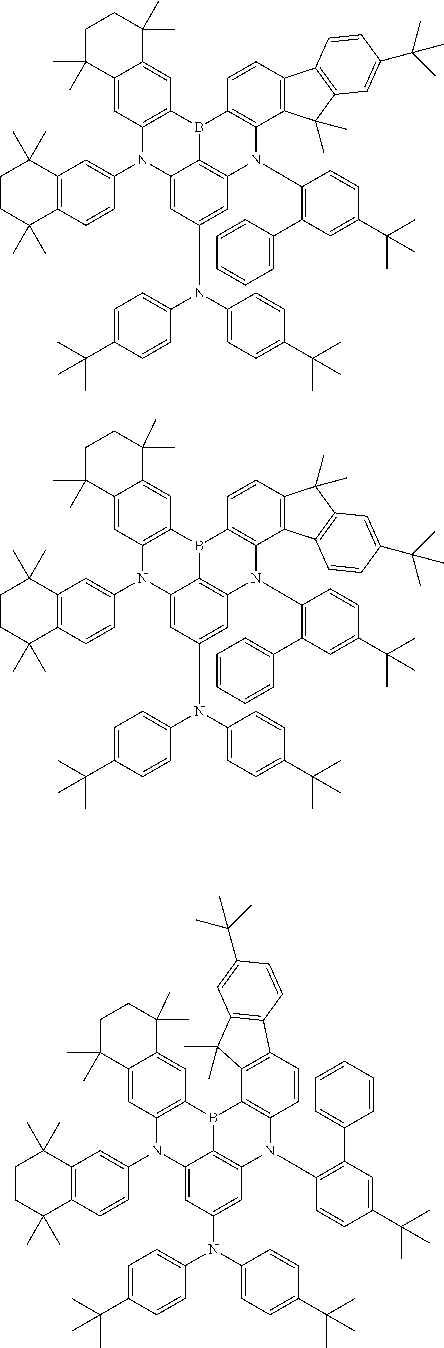

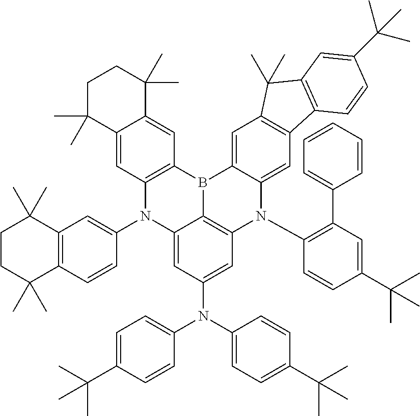 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)C(C)(C)c2cc(C(C)(C)C)ccc2-5)cc1]

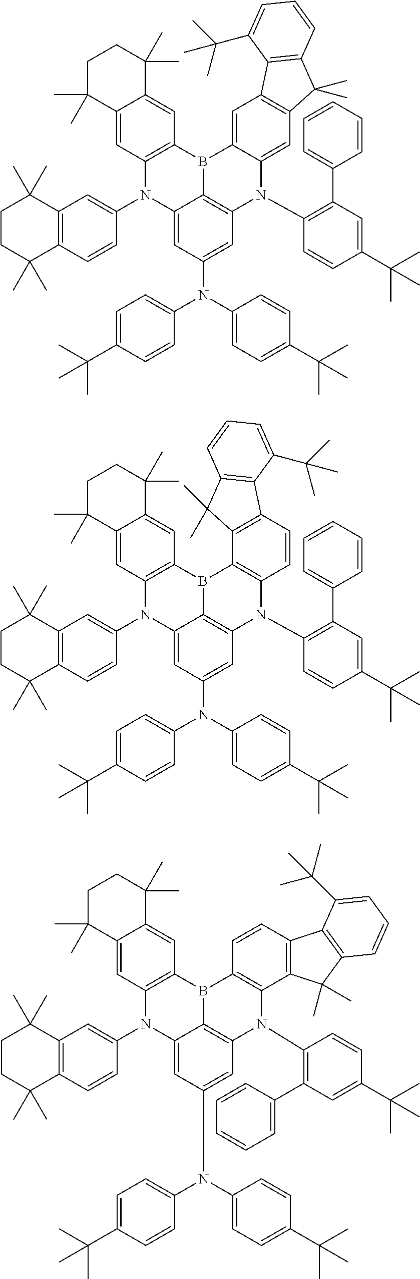

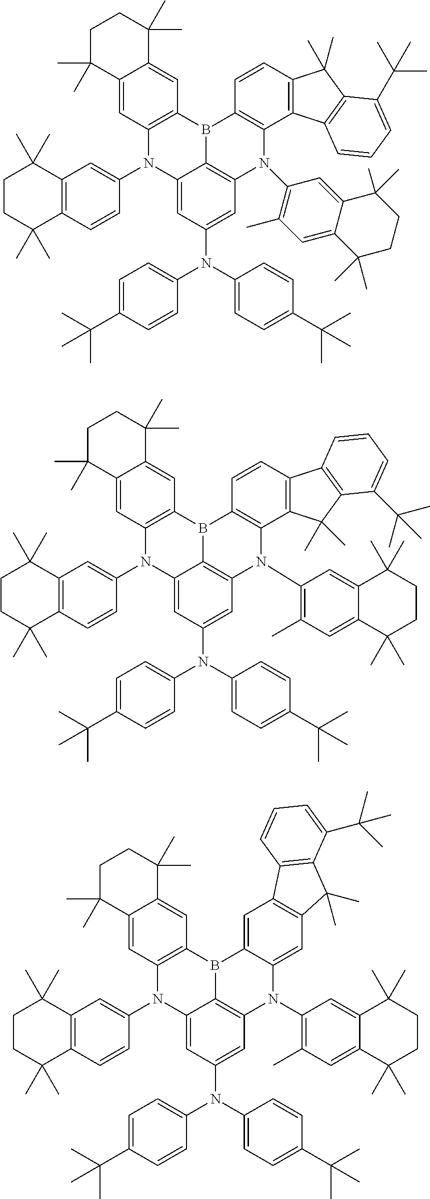

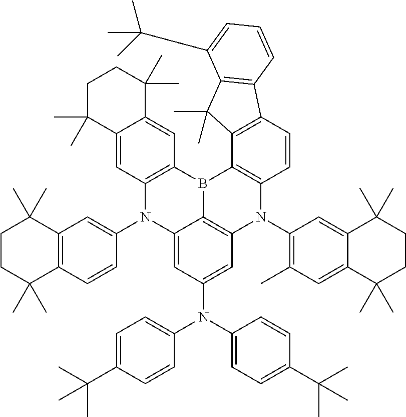 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3c1ccc1c3C(C)(C)c3c-1cccc3C(C)(C)C)C(C)(C)CCC2(C)C]

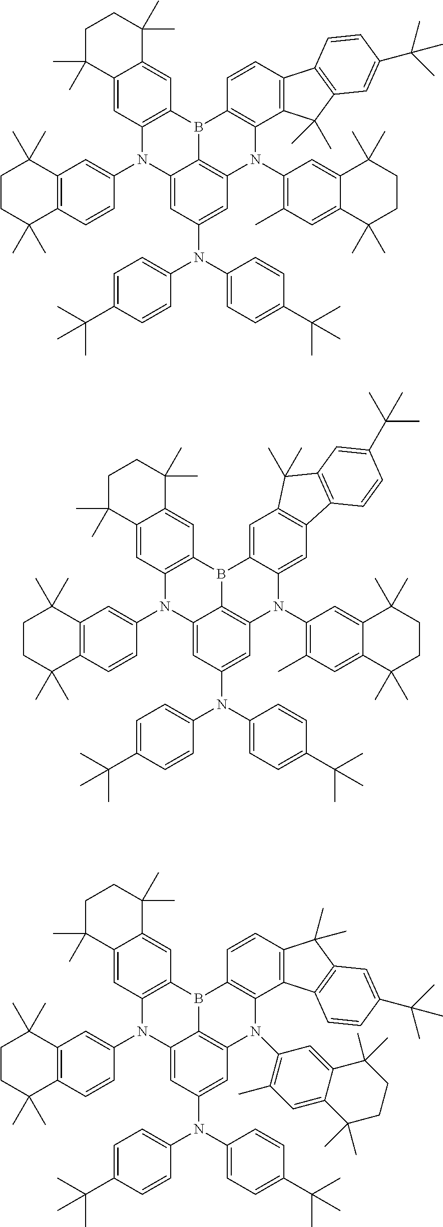

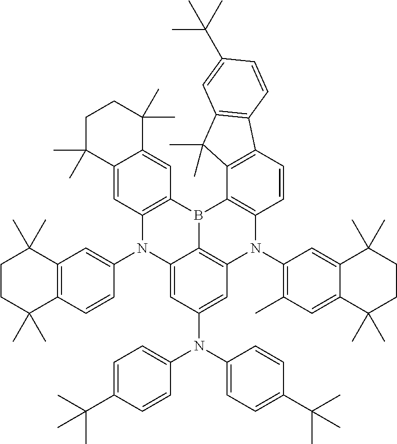 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3c1ccc1c3C(C)(C)c3cc(C(C)(C)C)ccc3-1)C(C)(C)CCC2(C)C]

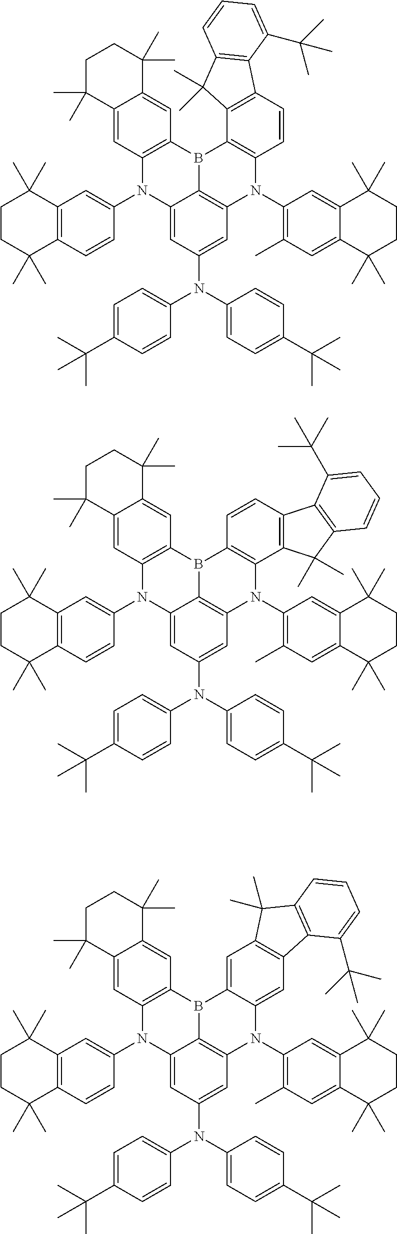

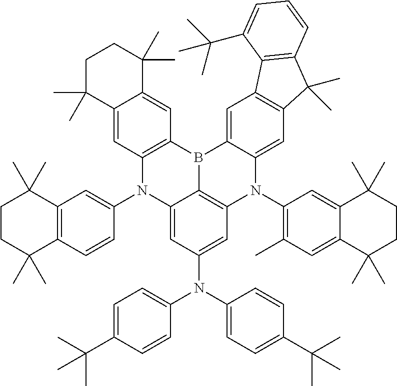 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)-c1c(C(C)(C)C)cccc1C4(C)C)C(C)(C)CCC2(C)C]

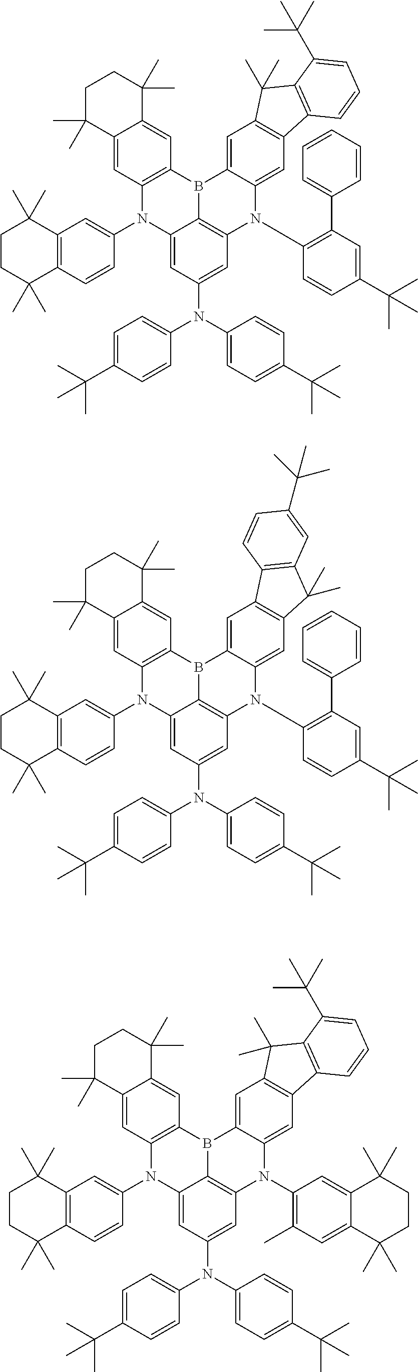

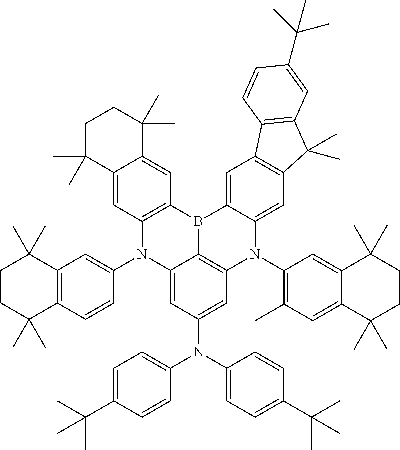 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)-c1ccc(C(C)(C)C)cc1C4(C)C)C(C)(C)CCC2(C)C]

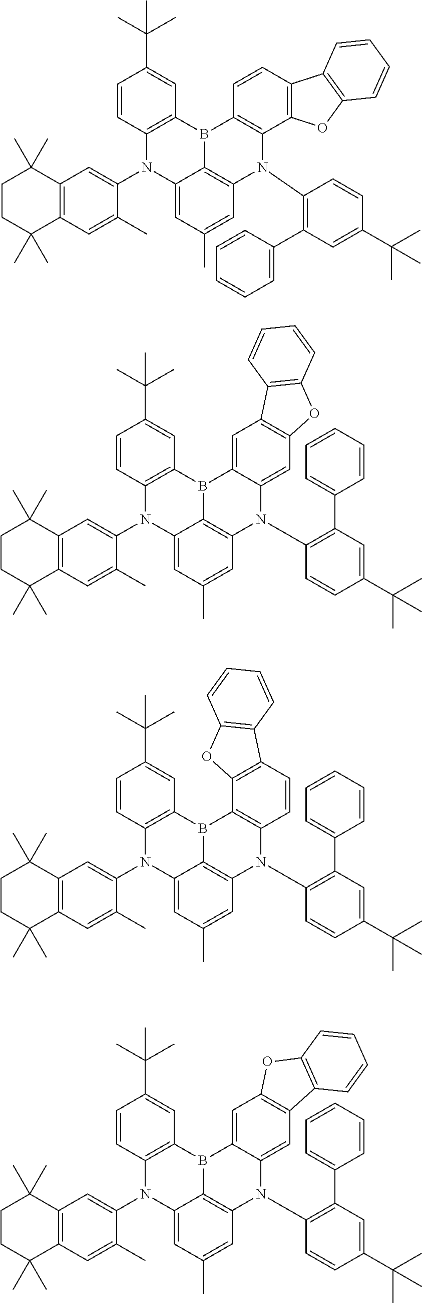

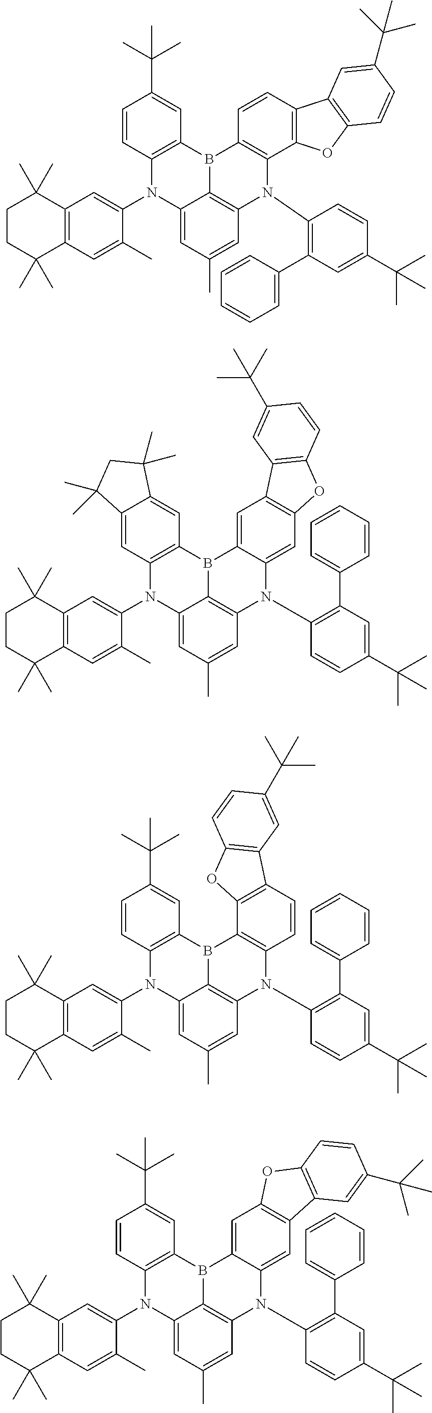

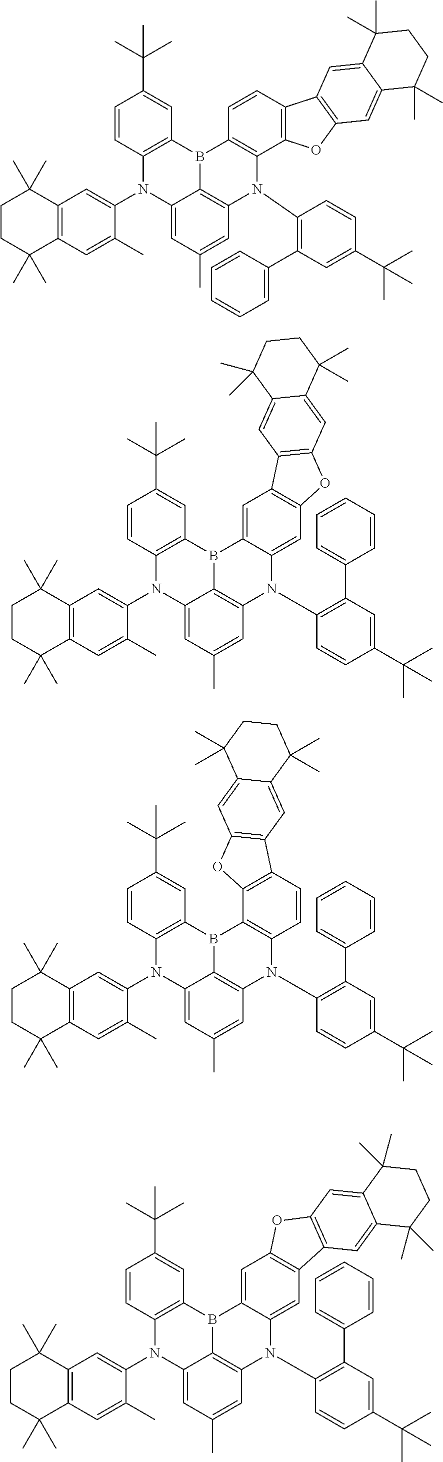

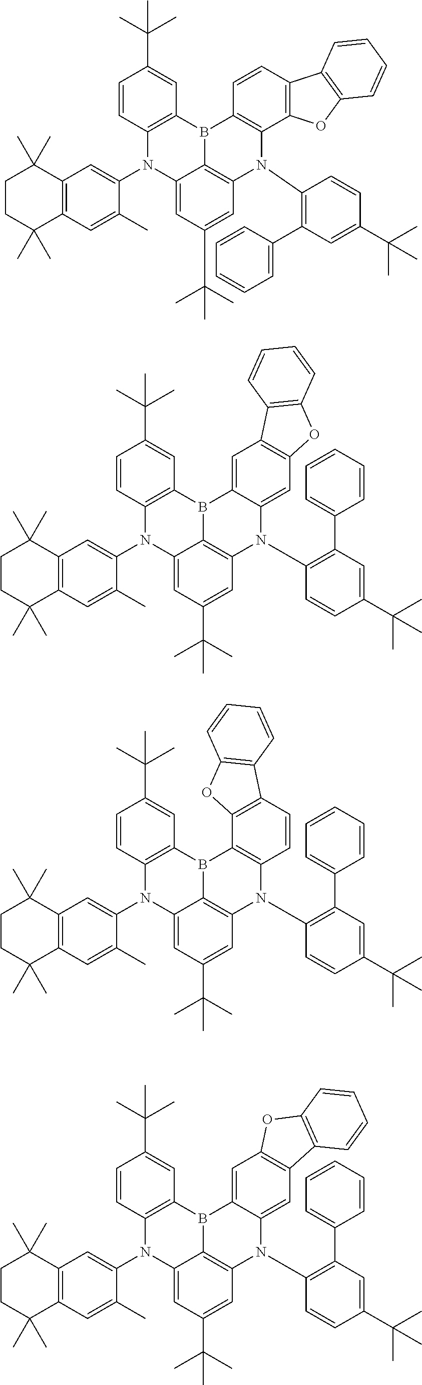

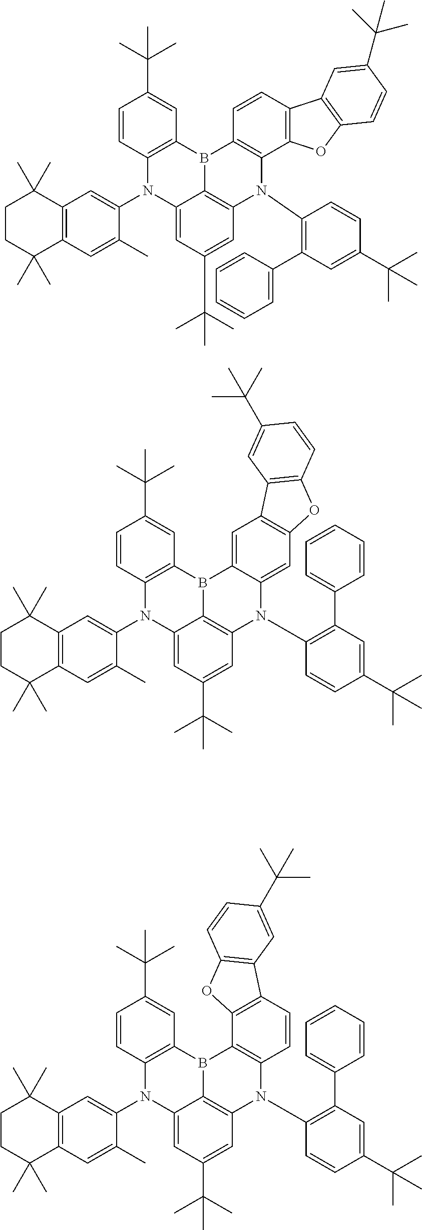

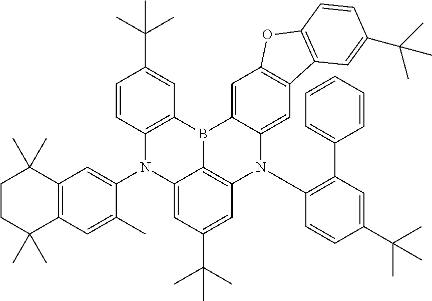 [SMILES: Cc1cc2c(cc1N1c3ccc(C(C)(C)C)cc3B3c4cc5oc6ccc(C(C)(C)C)cc6c5cc4N(c4ccc(C(C)(C)C)cc4-c4ccccc4)c4cc(C(C)(C)C)cc1c43)C(C)(C)CCC2(C)C]

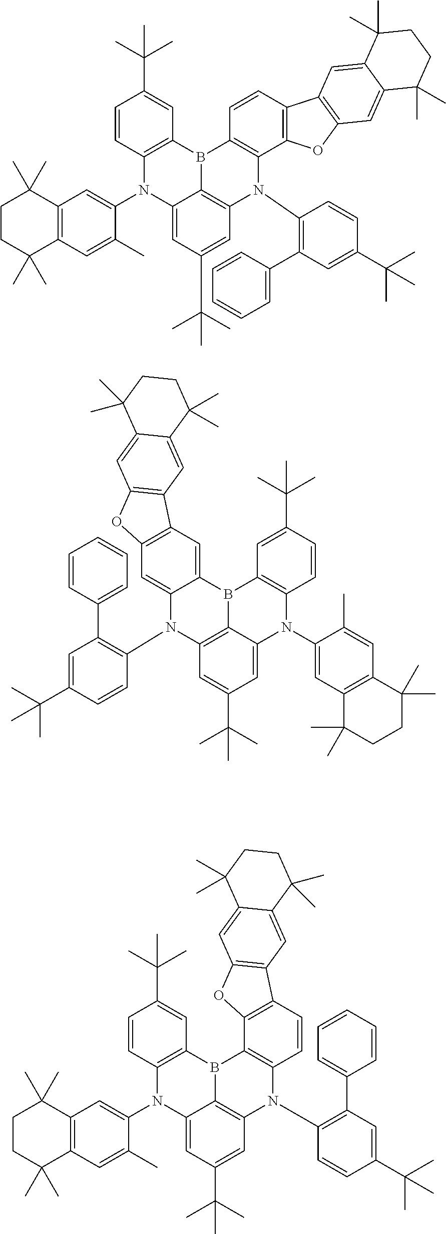

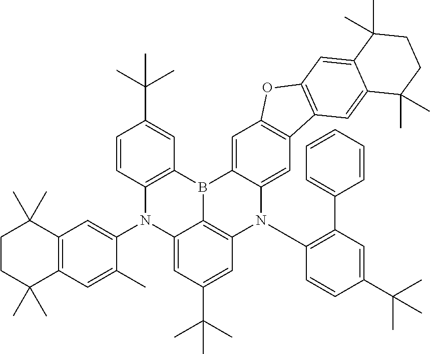 [SMILES: Cc1cc2c(cc1N1c3ccc(C(C)(C)C)cc3B3c4cc5oc6cc7c(cc6c5cc4N(c4ccc(C(C)(C)C)cc4-c4ccccc4)c4cc(C(C)(C)C)cc1c43)C(C)(C)CCC7(C)C)C(C)(C)CCC2(C)C]

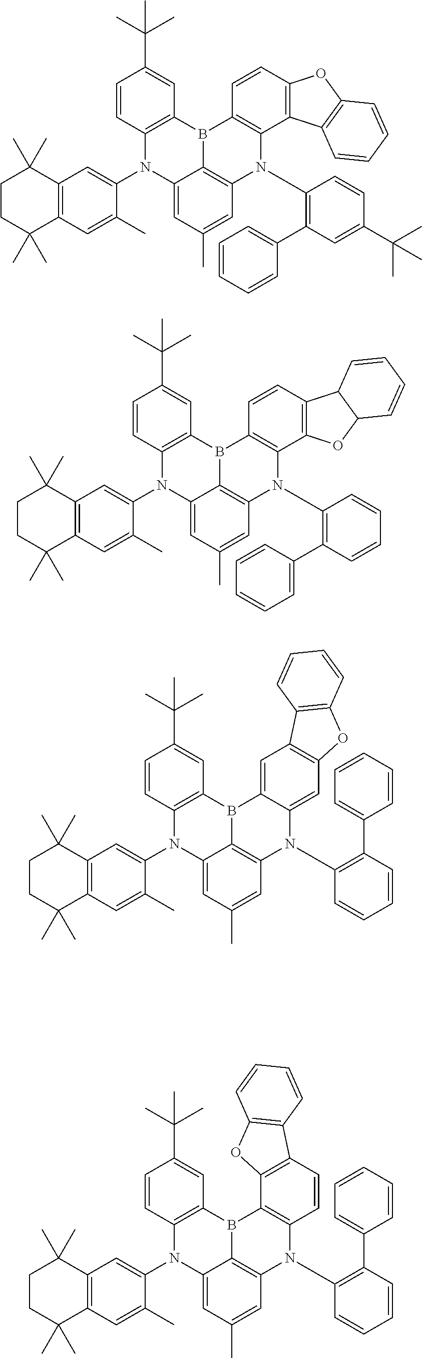 [SMILES: Cc1cc2c3c(c1)N(c1ccc(C(C)(C)C)cc1-c1ccccc1)c1c(ccc4oc5ccccc5c14)B3c1cc(C(C)(C)C)ccc1N2c1cc2c(cc1C)C(C)(C)CCC2(C)C ; Cc1cc2c3c(c1)N(c1ccccc1-c1ccccc1)c1c(ccc4c1OC1C=CC=CC41)B3c1cc(C(C)(C)C)ccc1N2c1cc2c(cc1C)C(C)(C)CCC2(C)C ; Cc1cc2c3c(c1)N(c1ccccc1-c1ccccc1)c1cc4oc5ccccc5c4cc1B3c1cc(C(C)(C)C)ccc1N2c1cc2c(cc1C)C(C)(C)CCC2(C)C ; Cc1cc2c3c(c1)N(c1ccccc1-c1ccccc1)c1ccc4c(oc5ccccc54)c1B3c1cc(C(C)(C)C)ccc1N2c1cc2c(cc1C)C(C)(C)CCC2(C)C]

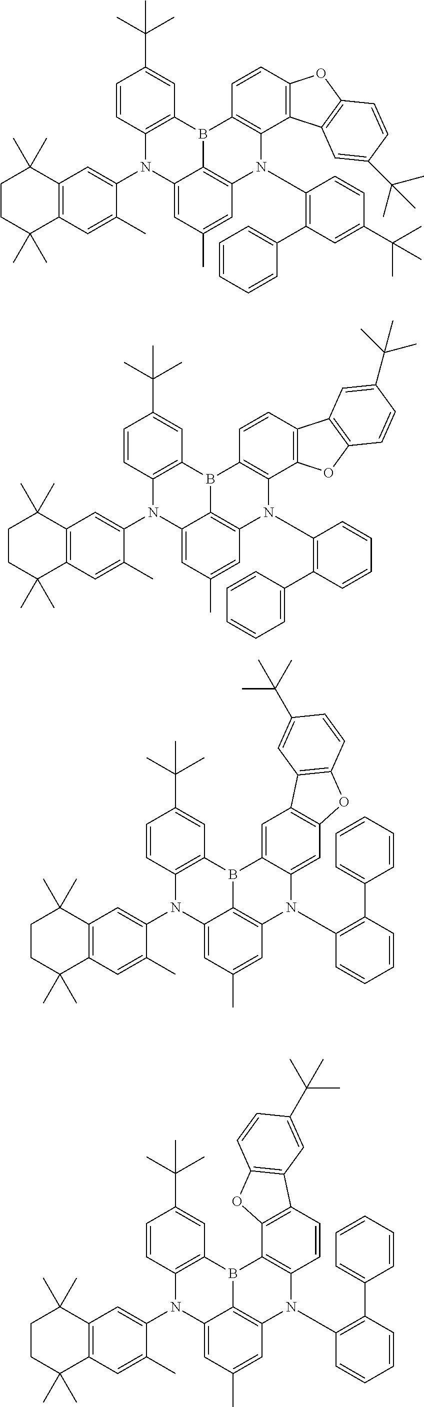

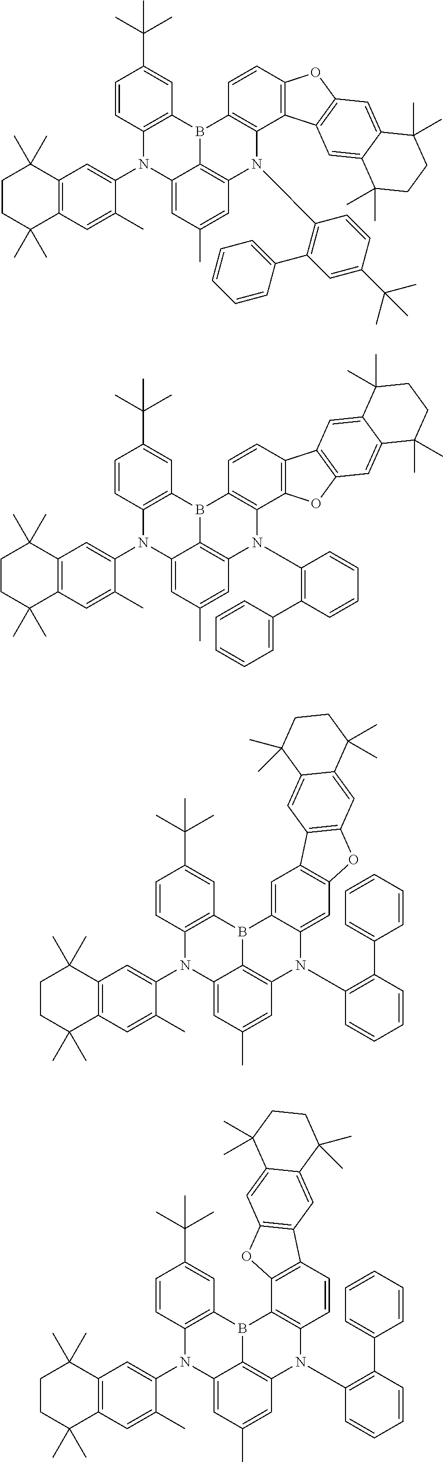

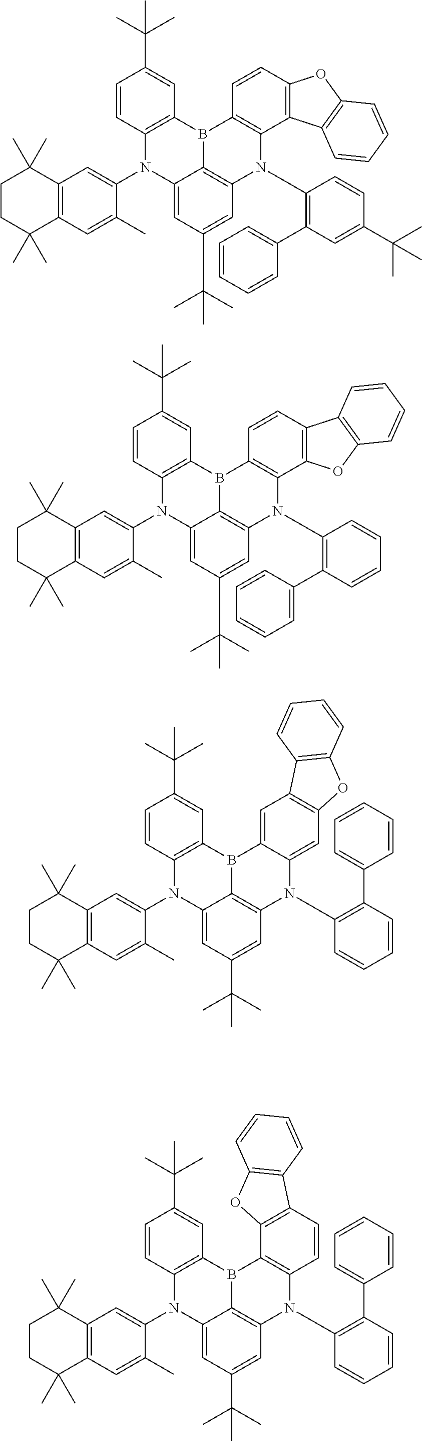

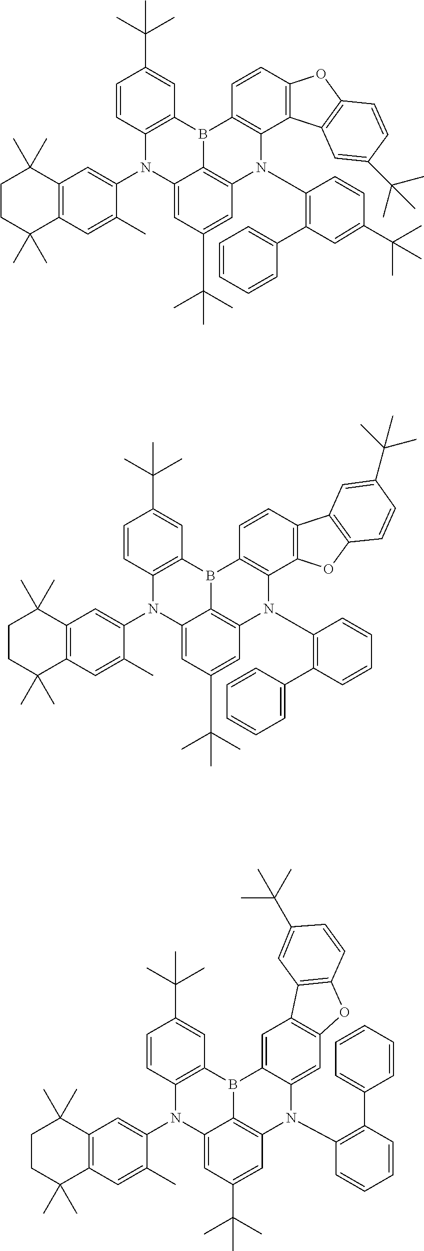 [SMILES: Cc1cc2c(cc1N1c3ccc(C(C)(C)C)cc3B3c4ccc5oc6ccc(C(C)(C)C)cc6c5c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(C(C)(C)C)cc1c43)oc1ccc(C(C)(C)C)cc15)C(C)(C)CCC2(C)C]

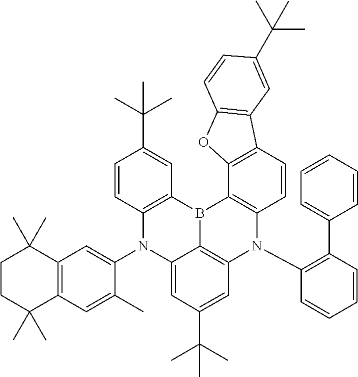 [SMILES: Cc1cc2c(cc1N1c3ccc(C(C)(C)C)cc3B3c4c1cc(C(C)(C)C)cc4N(c1ccccc1-c1ccccc1)c1ccc4c(oc5ccc(C(C)(C)C)cc54)c13)C(C)(C)CCC2(C)C]

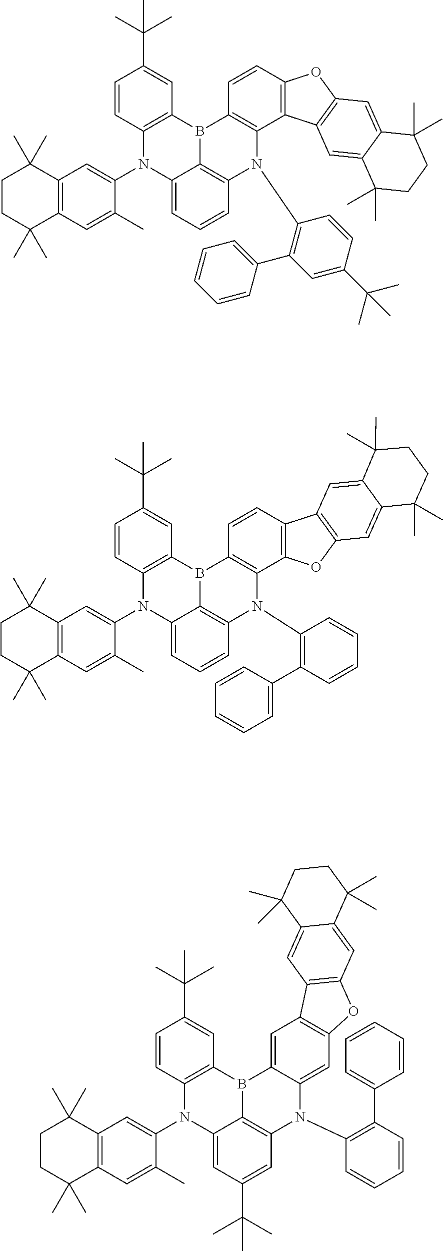 [SMILES: Cc1cc2c(cc1N1c3ccc(C(C)(C)C)cc3B3c4ccc5oc6cc7c(cc6c5c4N(c4ccc(C(C)(C)C)cc4-c4ccccc4)c4cccc1c43)C(C)(C)CCC7(C)C)C(C)(C)CCC2(C)C ; Cc1cc2c(cc1N1c3ccc(C(C)(C)C)cc3B3c4ccc5c(oc6cc7c(cc65)C(C)(C)CCC7(C)C)c4N(c4ccccc4-c4ccccc4)c4cccc1c43)C(C)(C)CCC2(C)C ; Cc1cc2c(cc1N1c3ccc(C(C)(C)C)cc3B3c4cc5c(cc4N(c4ccccc4-c4ccccc4)c4cc(C(C)(C)C)cc1c43)oc1cc3c(cc15)C(C)(C)CCC3(C)C)C(C)(C)CCC2(C)C]

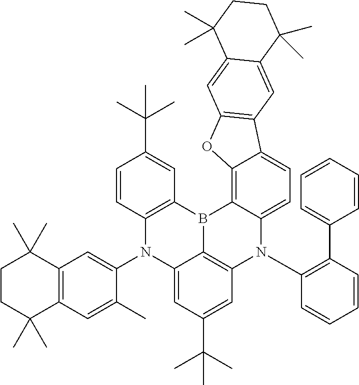 [SMILES: Cc1cc2c(cc1N1c3ccc(C(C)(C)C)cc3B3c4c1cc(C(C)(C)C)cc4N(c1ccccc1-c1ccccc1)c1ccc4c(oc5cc6c(cc54)C(C)(C)CCC6(C)C)c13)C(C)(C)CCC2(C)C]

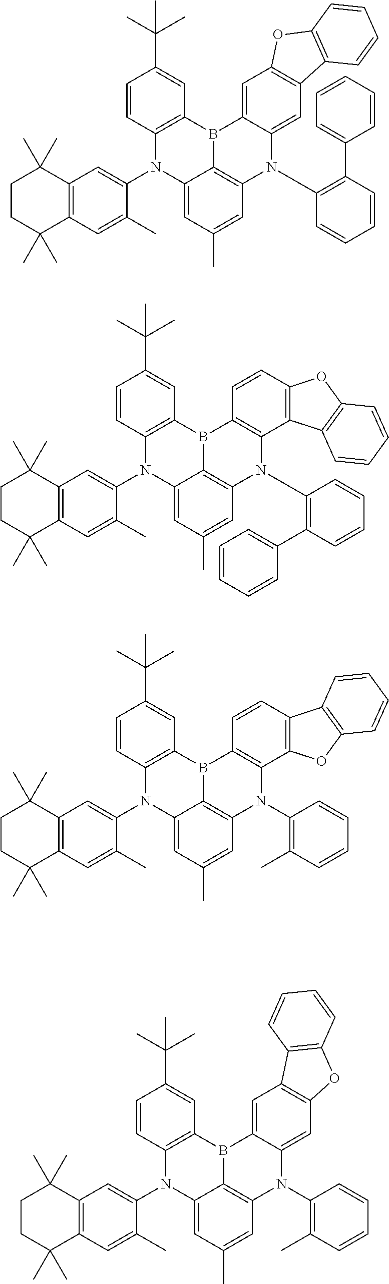 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1ccccc14 ; Cc1cc2c3c(c1)N(c1ccccc1-c1ccccc1)c1c(ccc4oc5ccccc5c14)B3c1cc(C(C)(C)C)ccc1N2c1cc2c(cc1C)C(C)(C)CCC2(C)C ; Cc1cc2c3c(c1)N(c1ccccc1C)c1c(ccc4c1oc1ccccc14)B3c1cc(C(C)(C)C)ccc1N2c1cc2c(cc1C)C(C)(C)CCC2(C)C ; Cc1cc2c3c(c1)N(c1ccccc1C)c1cc4oc5ccccc5c4cc1B3c1cc(C(C)(C)C)ccc1N2c1cc2c(cc1C)C(C)(C)CCC2(C)C]

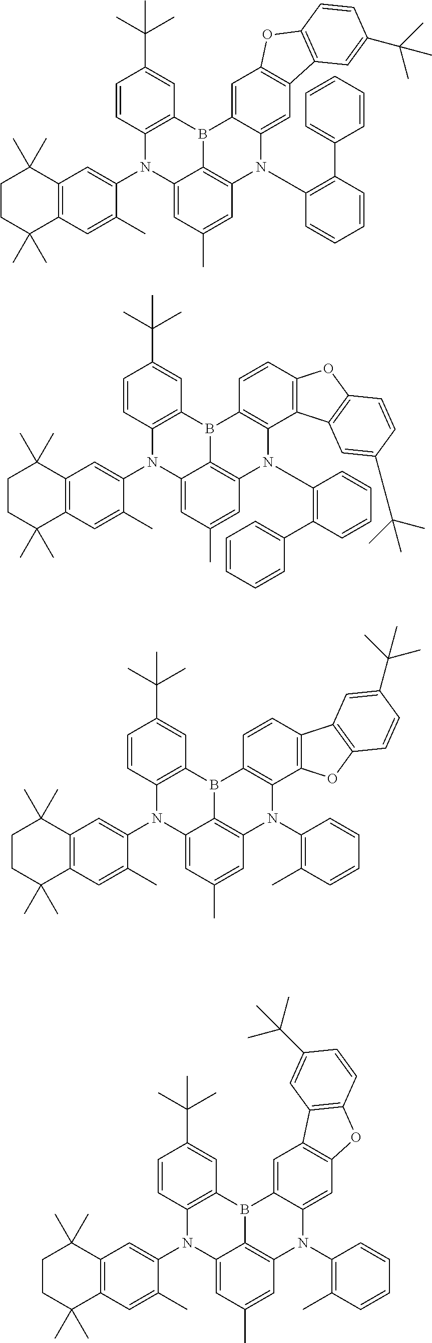 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1ccc(C(C)(C)C)cc14 ; Cc1cc2c3c(c1)N(c1ccccc1-c1ccccc1)c1c(ccc4oc5ccc(C(C)(C)C)cc5c14)B3c1cc(C(C)(C)C)ccc1N2c1cc2c(cc1C)C(C)(C)CCC2(C)C ; Cc1cc2c3c(c1)N(c1ccccc1C)c1c(ccc4c1oc1ccc(C(C)(C)C)cc14)B3c1cc(C(C)(C)C)ccc1N2c1cc2c(cc1C)C(C)(C)CCC2(C)C ; Cc1cc2c3c(c1)N(c1ccccc1C)c1cc4oc5ccc(C(C)(C)C)cc5c4cc1B3c1cc(C(C)(C)C)ccc1N2c1cc2c(cc1C)C(C)(C)CCC2(C)C]

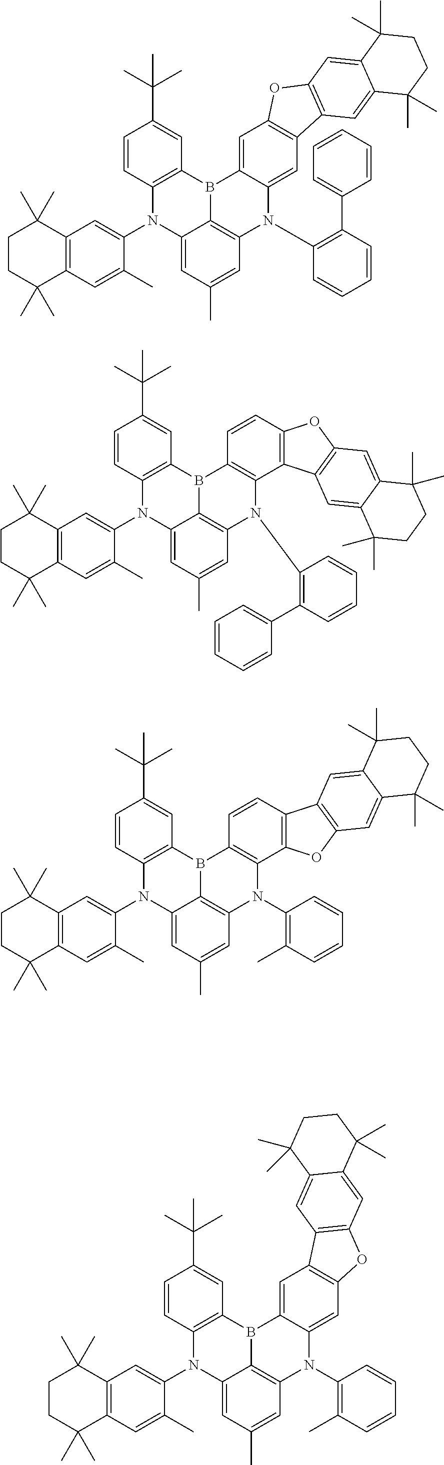 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1cc2c3c(c1)N(c1ccccc1-c1ccccc1)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1cc2c3c(c1)N(c1ccccc1C)c1c(ccc4c1oc1cc5c(cc14)C(C)(C)CCC5(C)C)B3c1cc(C(C)(C)C)ccc1N2c1cc2c(cc1C)C(C)(C)CCC2(C)C ; Cc1cc2c3c(c1)N(c1ccccc1C)c1cc4oc5cc6c(cc5c4cc1B3c1cc(C(C)(C)C)ccc1N2c1cc2c(cc1C)C(C)(C)CCC2(C)C)C(C)(C)CCC6(C)C]

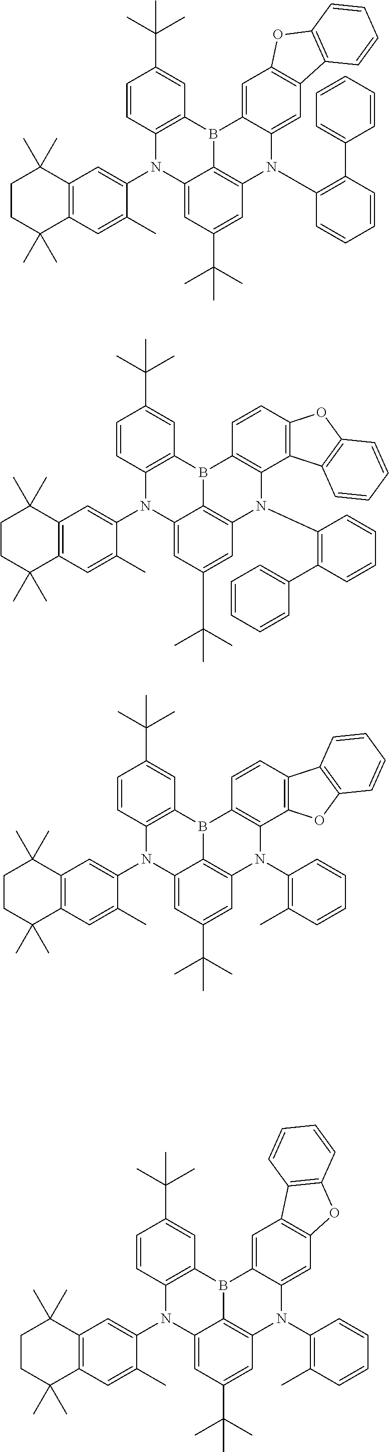 [SMILES: Cc1cc2c(cc1N1c3ccc(C(C)(C)C)cc3B3c4cc5oc6ccccc6c5cc4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5oc6ccccc6c5c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(oc6ccccc65)c4N(c4ccccc4C)c4cc(C(C)(C)C)cc1c43)C(C)(C)CCC2(C)C ; Cc1ccccc1N1c2cc3oc4ccccc4c3cc2B2c3cc(C(C)(C)C)ccc3N(c3cc4c(cc3C)C(C)(C)CCC4(C)C)c3cc(C(C)(C)C)cc1c32]

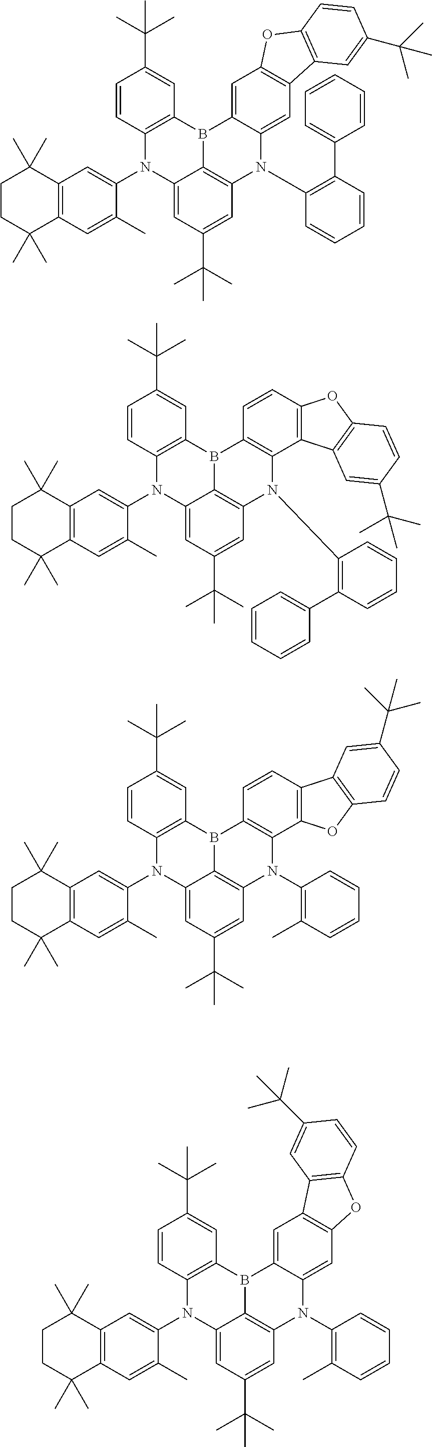

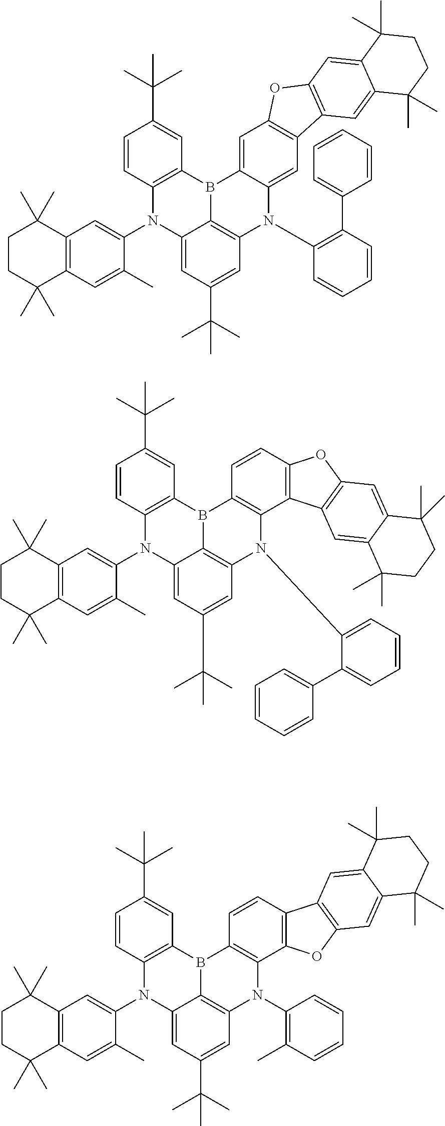 [SMILES: Cc1cc2c(cc1N1c3ccc(C(C)(C)C)cc3B3c4cc5oc6cc7c(cc6c5cc4N(c4ccccc4-c4ccccc4)c4cc(C(C)(C)C)cc1c43)C(C)(C)CCC7(C)C)C(C)(C)CCC2(C)C ; Cc1cc2c(cc1N1c3ccc(C(C)(C)C)cc3B3c4ccc5oc6cc7c(cc6c5c4N(c4ccccc4-c4ccccc4)c4cc(C(C)(C)C)cc1c43)C(C)(C)CCC7(C)C)C(C)(C)CCC2(C)C ; Cc1cc2c(cc1N1c3ccc(C(C)(C)C)cc3B3c4ccc5c(oc6cc7c(cc65)C(C)(C)CCC7(C)C)c4N(c4ccccc4C)c4cc(C(C)(C)C)cc1c43)C(C)(C)CCC2(C)C]

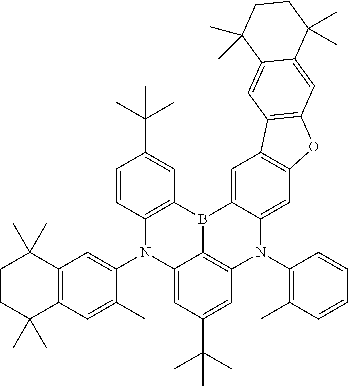 [SMILES: Cc1ccccc1N1c2cc3oc4cc5c(cc4c3cc2B2c3cc(C(C)(C)C)ccc3N(c3cc4c(cc3C)C(C)(C)CCC4(C)C)c3cc(C(C)(C)C)cc1c32)C(C)(C)CCC5(C)C]

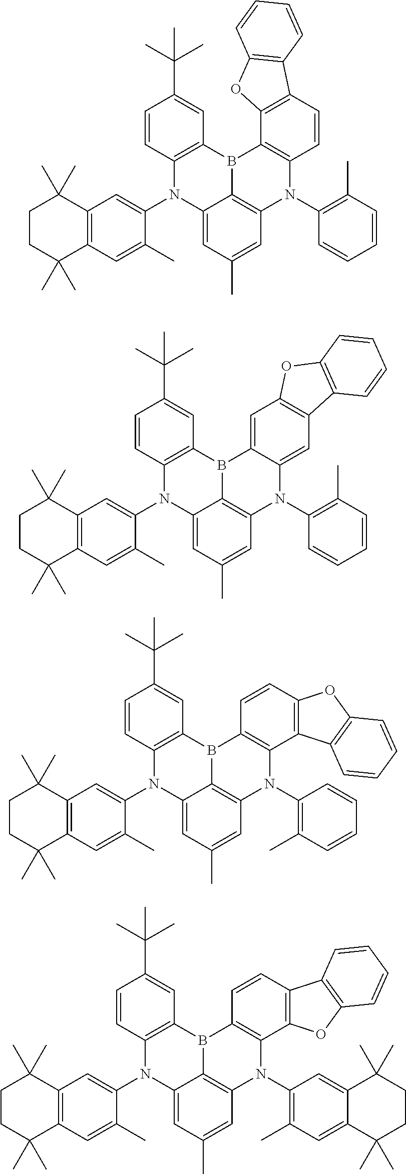 [SMILES: Cc1cc2c3c(c1)N(c1ccccc1C)c1ccc4c(oc5ccccc54)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)oc1ccccc14 ; Cc1cc2c3c(c1)N(c1ccccc1C)c1c(ccc4oc5ccccc5c14)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1oc1ccccc14)B3c1cc(C(C)(C)C)ccc1N2c1cc2c(cc1C)C(C)(C)CCC2(C)C]

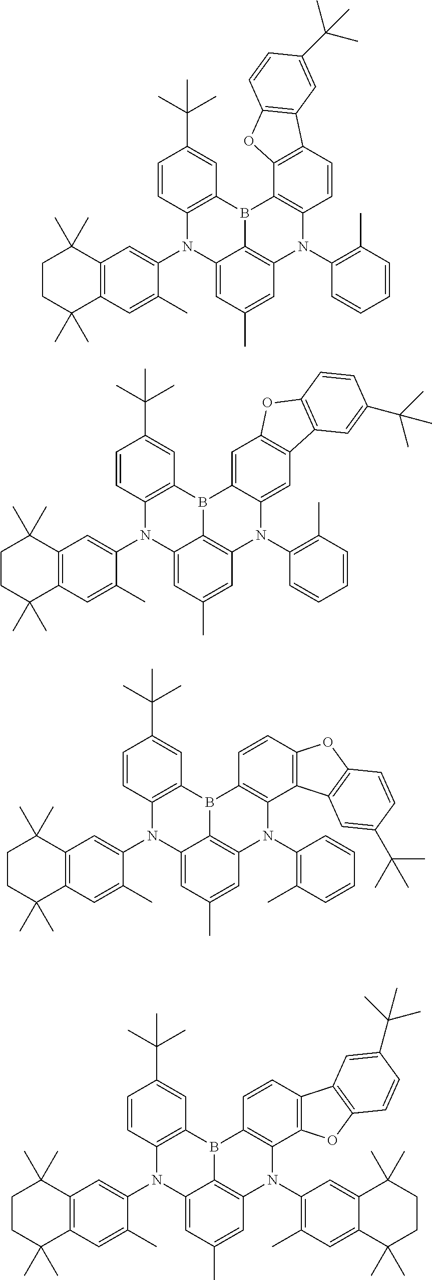 [SMILES: Cc1cc2c3c(c1)N(c1ccccc1C)c1ccc4c(oc5ccc(C(C)(C)C)cc54)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)oc1ccc(C(C)(C)C)cc14 ; Cc1cc2c3c(c1)N(c1ccccc1C)c1c(ccc4oc5ccc(C(C)(C)C)cc5c14)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1oc1ccc(C(C)(C)C)cc14)B3c1cc(C(C)(C)C)ccc1N2c1cc2c(cc1C)C(C)(C)CCC2(C)C]

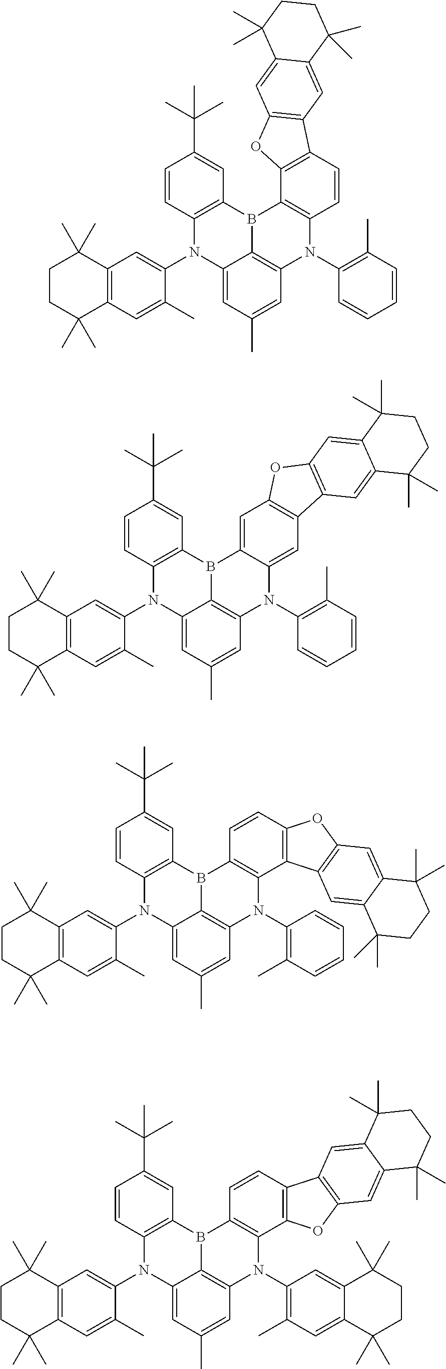 [SMILES: Cc1cc2c3c(c1)N(c1ccccc1C)c1ccc4c(oc5cc6c(cc54)C(C)(C)CCC6(C)C)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1cc2c3c(c1)N(c1ccccc1C)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc(C(C)(C)C)ccc1N2c1cc2c(cc1C)C(C)(C)CCC2(C)C]

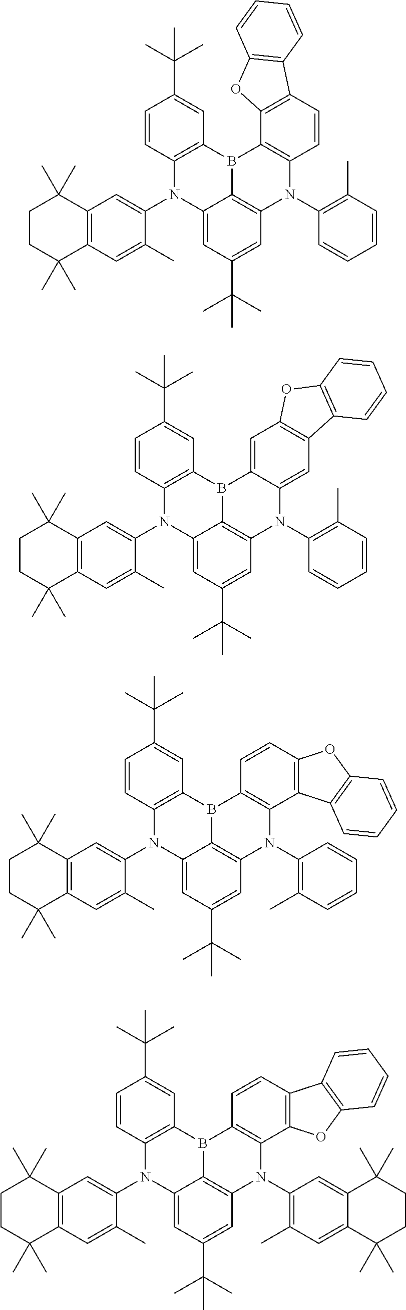 [SMILES: Cc1cc2c(cc1N1c3ccc(C(C)(C)C)cc3B3c4c1cc(C(C)(C)C)cc4N(c1ccccc1C)c1ccc4c(oc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(C(C)(C)C)cc1c42)oc1ccccc13 ; Cc1cc2c(cc1N1c3ccc(C(C)(C)C)cc3B3c4ccc5oc6ccccc6c5c4N(c4ccccc4C)c4cc(C(C)(C)C)cc1c43)C(C)(C)CCC2(C)C ; Cc1cc2c(cc1N1c3ccc(C(C)(C)C)cc3B3c4ccc5c(oc6ccccc65)c4N(c4cc5c(cc4C)C(C)(C)CCC5(C)C)c4cc(C(C)(C)C)cc1c43)C(C)(C)CCC2(C)C]

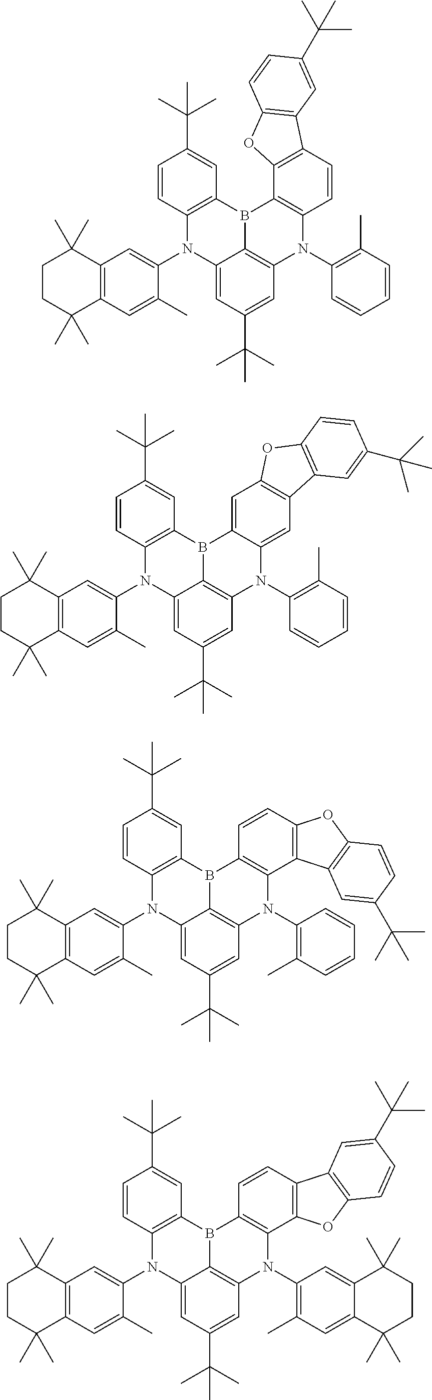 [SMILES: Cc1cc2c(cc1N1c3ccc(C(C)(C)C)cc3B3c4c1cc(C(C)(C)C)cc4N(c1ccccc1C)c1ccc4c(oc5ccc(C(C)(C)C)cc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(C(C)(C)C)cc1c42)oc1ccc(C(C)(C)C)cc13 ; Cc1cc2c(cc1N1c3ccc(C(C)(C)C)cc3B3c4ccc5oc6ccc(C(C)(C)C)cc6c5c4N(c4ccccc4C)c4cc(C(C)(C)C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4cc5c(cc4C)C(C)(C)CCC5(C)C)c4cc(C(C)(C)C)cc1c43)C(C)(C)CCC2(C)C]

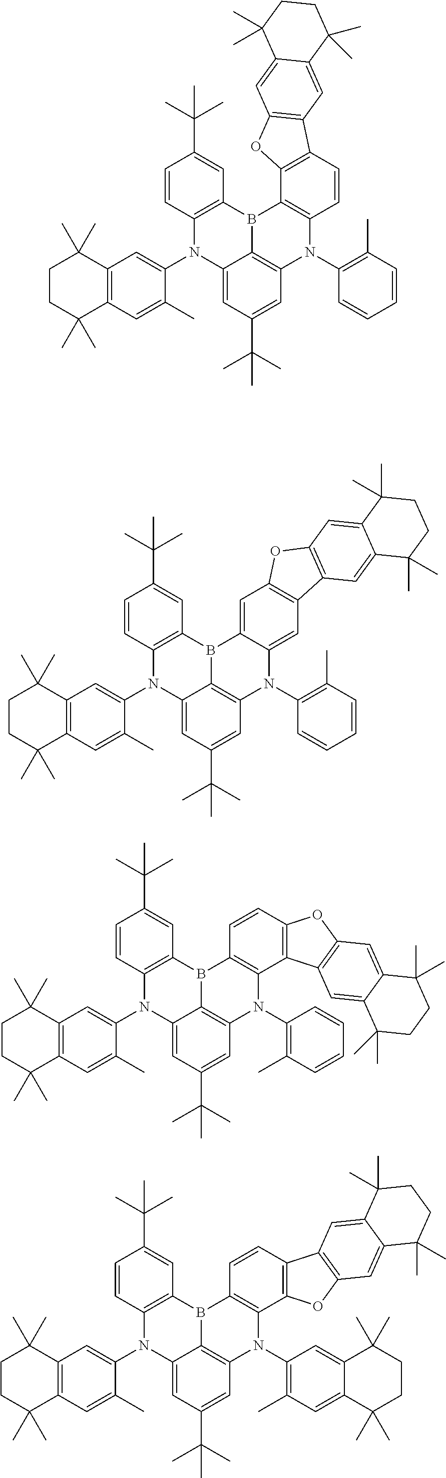

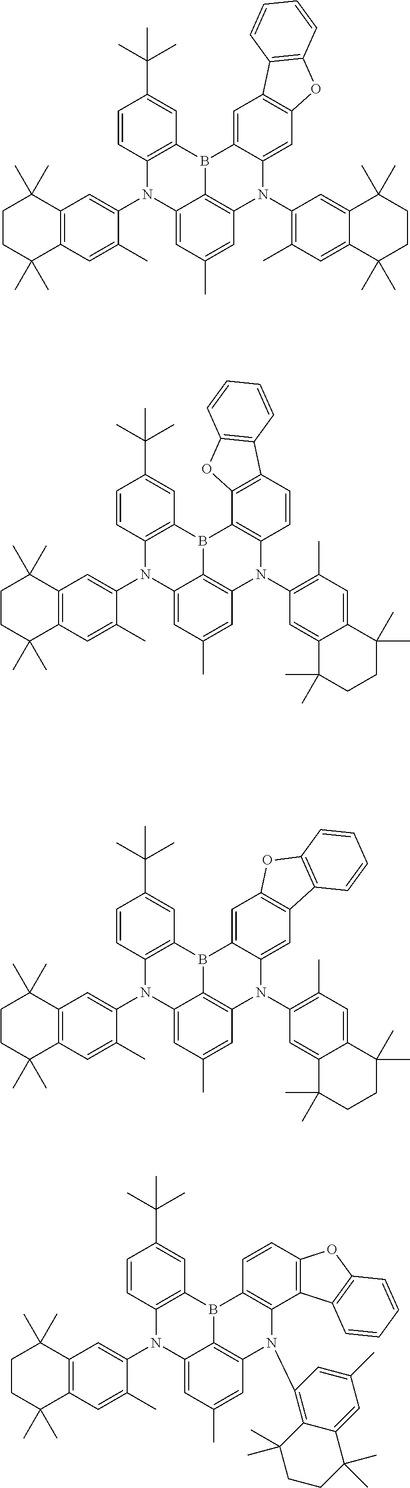 [SMILES: Cc1cc2c3c(c1)N(c1cc4c(cc1C)C(C)(C)CCC4(C)C)c1cc4oc5ccccc5c4cc1B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1ccc4c(oc5ccccc54)c1B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1ccccc14 ; Cc1cc2c3c(c1)N(c1cc(C)cc4c1C(C)(C)CCC4(C)C)c1c(ccc4oc5ccccc5c14)B3c1cc(C(C)(C)C)ccc1N2c1cc2c(cc1C)C(C)(C)CCC2(C)C]

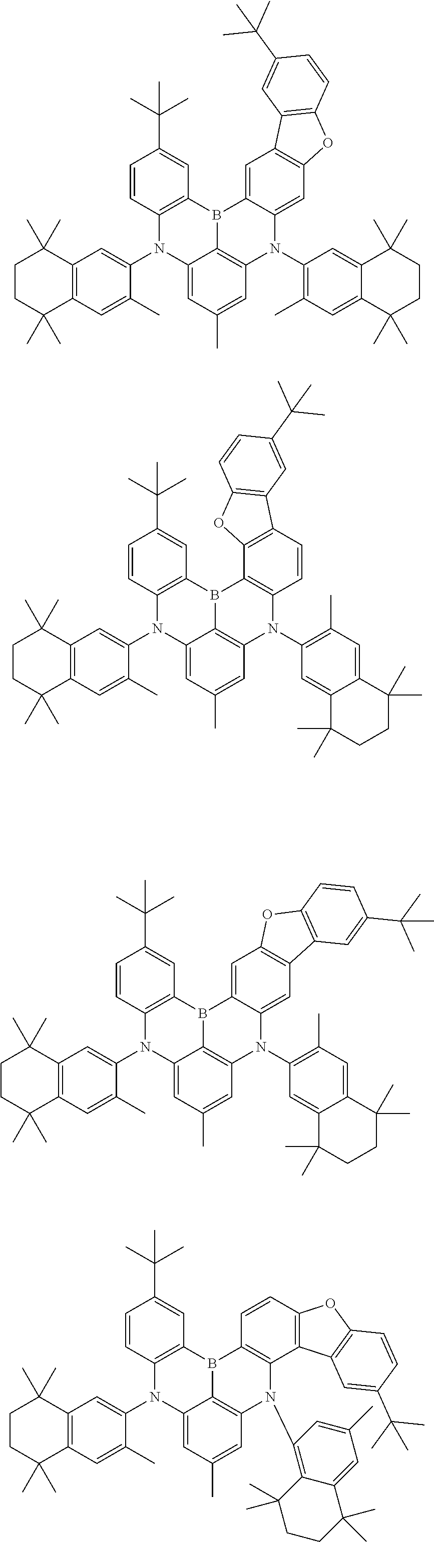 [SMILES: Cc1cc2c3c(c1)N(c1cc4c(cc1C)C(C)(C)CCC4(C)C)c1cc4oc5ccc(C(C)(C)C)cc5c4cc1B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1ccc4c(oc5ccc(C(C)(C)C)cc54)c1B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1ccc(C(C)(C)C)cc14 ; Cc1cc2c3c(c1)N(c1cc(C)cc4c1C(C)(C)CCC4(C)C)c1c(ccc4oc5ccc(C(C)(C)C)cc5c14)B3c1cc(C(C)(C)C)ccc1N2c1cc2c(cc1C)C(C)(C)CCC2(C)C]

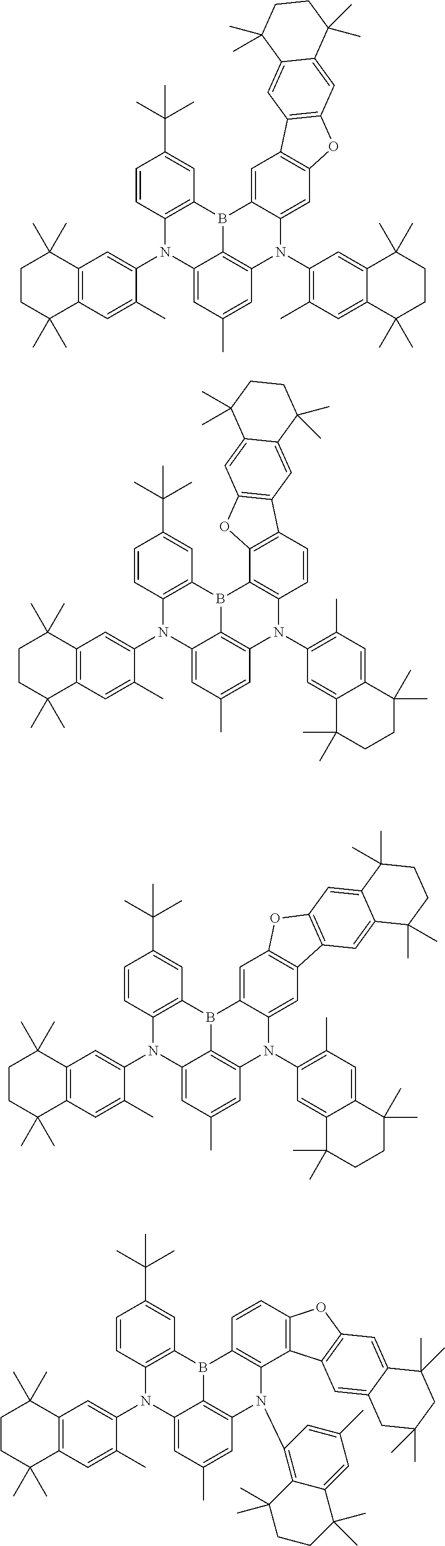

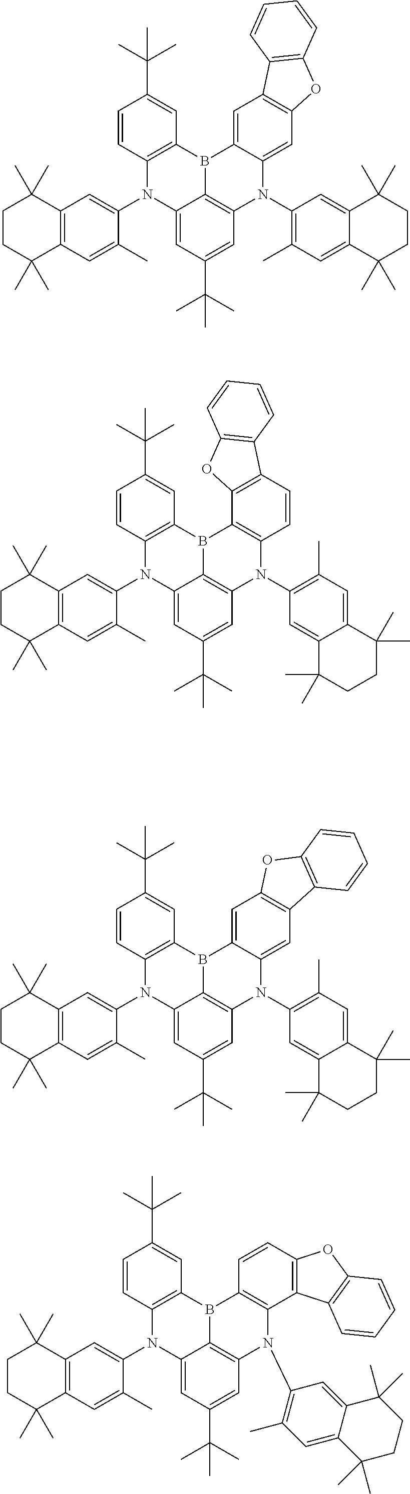 [SMILES: Cc1cc2c(cc1N1c3ccc(C(C)(C)C)cc3B3c4cc5c(cc4N(c4cc6c(cc4C)C(C)(C)CCC6(C)C)c4cc(C(C)(C)C)cc1c43)oc1ccccc15)C(C)(C)CCC2(C)C ; Cc1cc2c(cc1N1c3ccc(C(C)(C)C)cc3B3c4c1cc(C(C)(C)C)cc4N(c1cc4c(cc1C)C(C)(C)CCC4(C)C)c1ccc4c(oc5ccccc54)c13)C(C)(C)CCC2(C)C ; Cc1cc2c(cc1N1c3ccc(C(C)(C)C)cc3B3c4cc5oc6ccccc6c5cc4N(c4cc5c(cc4C)C(C)(C)CCC5(C)C)c4cc(C(C)(C)C)cc1c43)C(C)(C)CCC2(C)C ; Cc1cc2c(cc1N1c3ccc(C(C)(C)C)cc3B3c4ccc5oc6ccccc6c5c4N(c4cc5c(cc4C)C(C)(C)CCC5(C)C)c4cc(C(C)(C)C)cc1c43)C(C)(C)CCC2(C)C]

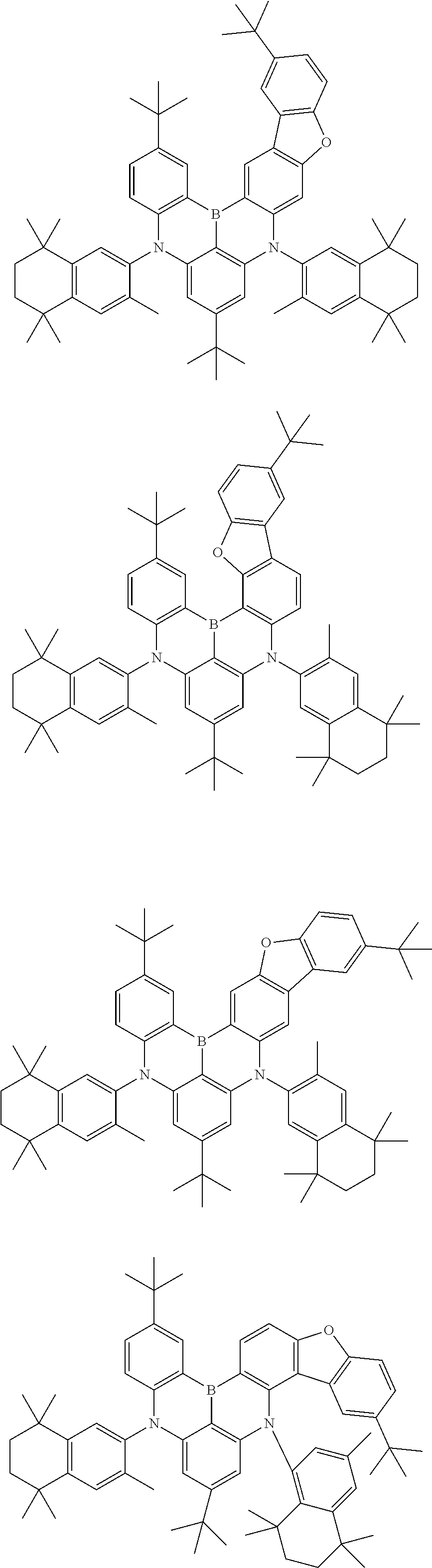

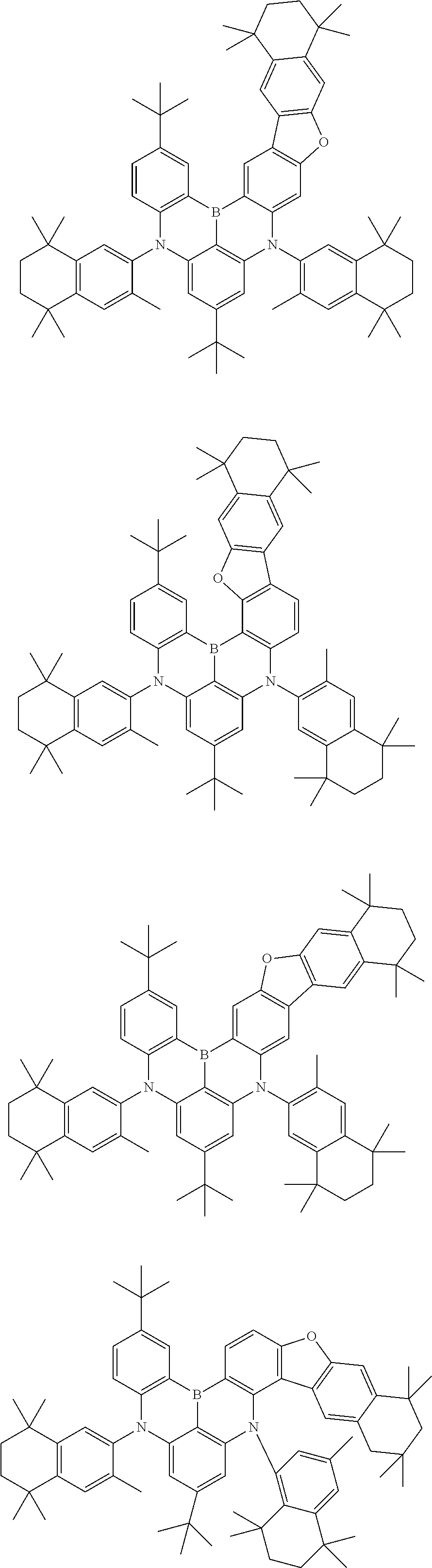

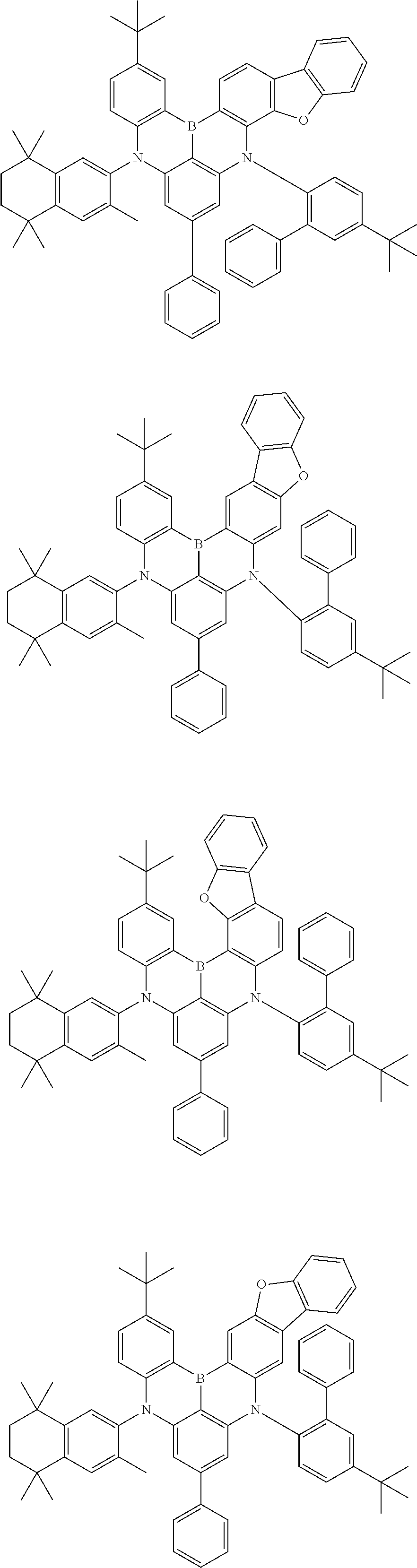 [SMILES: Cc1cc2c(cc1N1c3ccc(C(C)(C)C)cc3B3c4ccc5c(oc6ccccc65)c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6ccccc6)cc1c43)oc1ccccc15)C(C)(C)CCC2(C)C ; Cc1cc2c(cc1N1c3ccc(C(C)(C)C)cc3B3c4c1cc(-c1ccccc1)cc4N(c1ccc(C(C)(C)C)cc1-c1ccccc1)c1ccc4c(oc5ccccc54)c13)C(C)(C)CCC2(C)C ; Cc1cc2c(cc1N1c3ccc(C(C)(C)C)cc3B3c4cc5oc6ccccc6c5cc4N(c4ccc(C(C)(C)C)cc4-c4ccccc4)c4cc(-c5ccccc5)cc1c43)C(C)(C)CCC2(C)C]

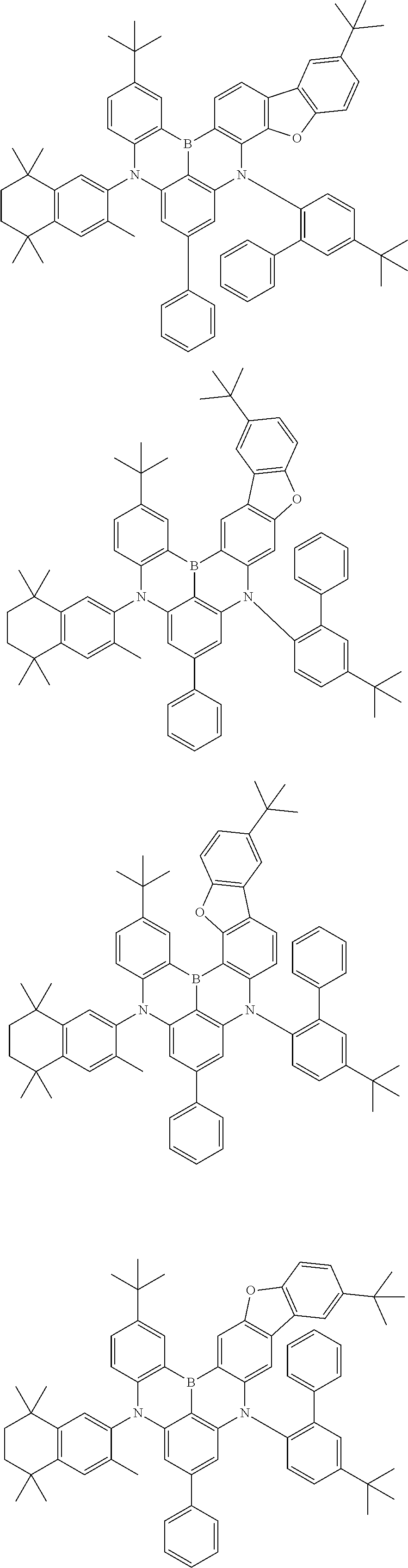

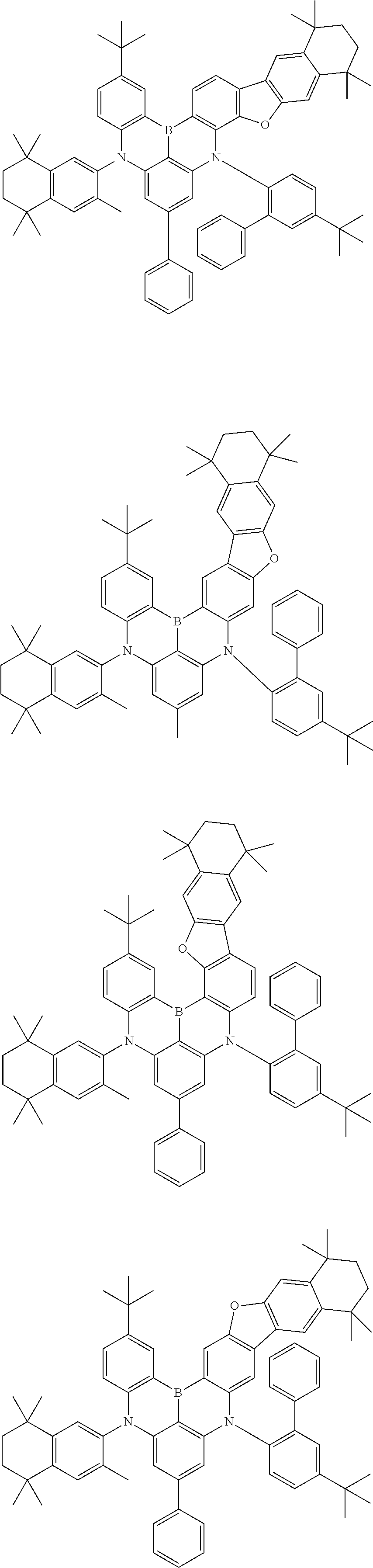

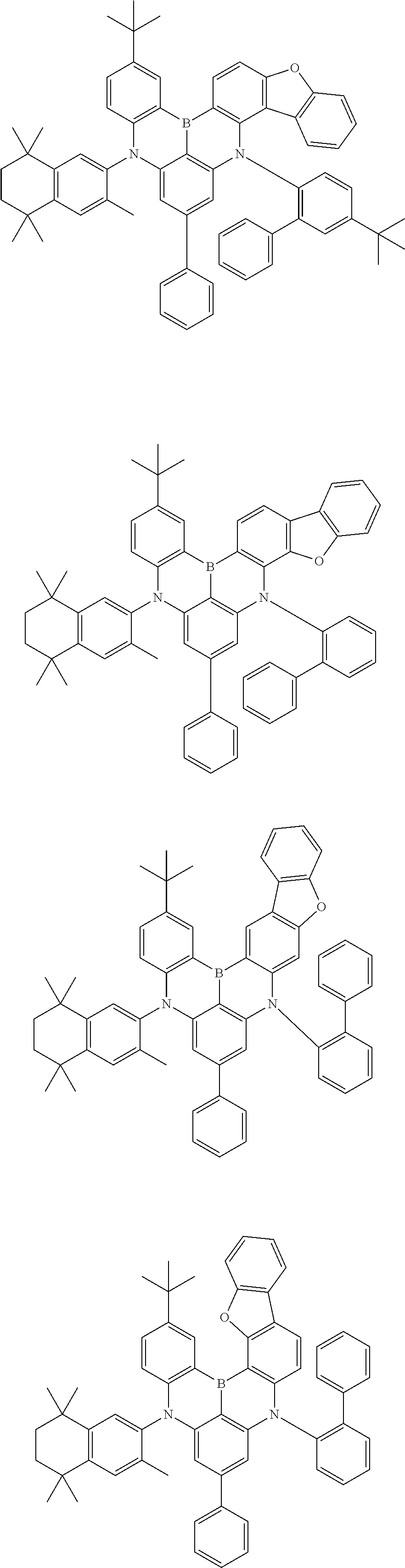 [SMILES: Cc1cc2c(cc1N1c3ccc(C(C)(C)C)cc3B3c4ccc5oc6ccccc6c5c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(oc6ccccc65)c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(-c6ccccc6)cc1c43)oc1ccccc15)C(C)(C)CCC2(C)C ; Cc1cc2c(cc1N1c3ccc(C(C)(C)C)cc3B3c4c1cc(-c1ccccc1)cc4N(c1ccccc1-c1ccccc1)c1ccc4c(oc5ccccc54)c13)C(C)(C)CCC2(C)C]

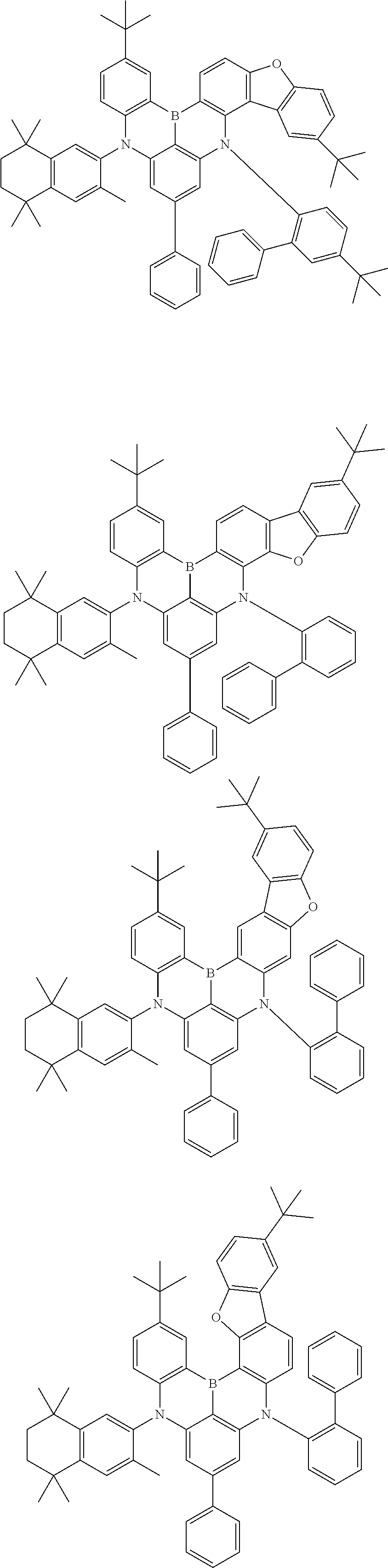

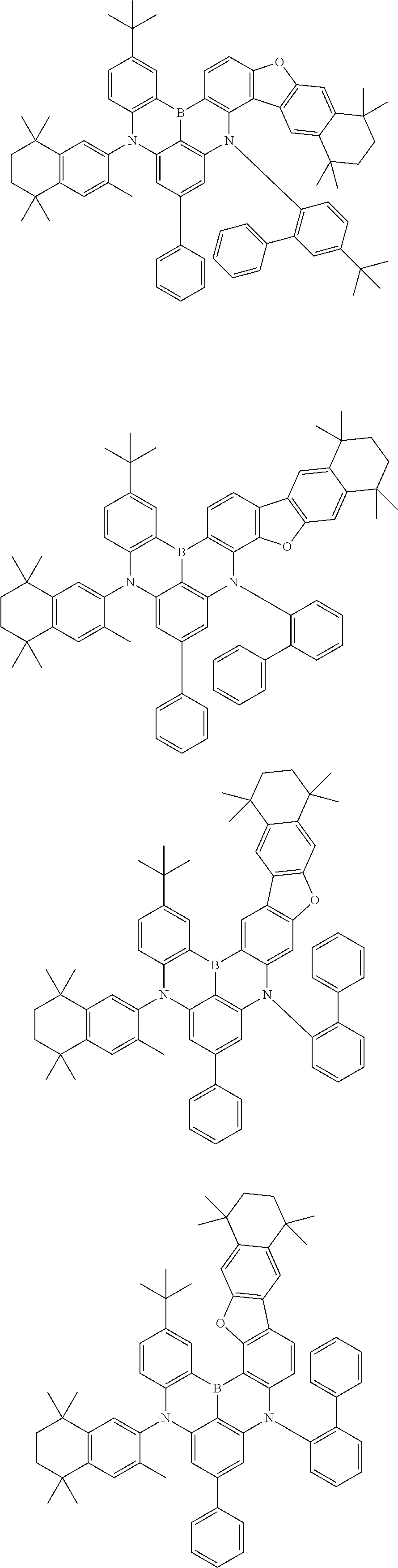

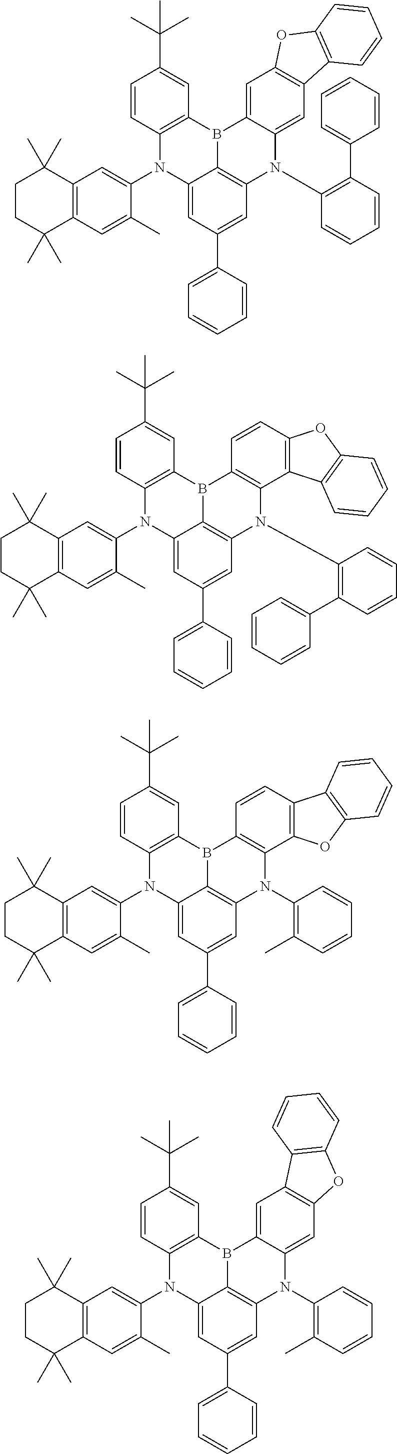 [SMILES: Cc1cc2c(cc1N1c3ccc(C(C)(C)C)cc3B3c4cc5oc6ccccc6c5cc4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4ccc5oc6ccccc6c5c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(oc6ccccc65)c4N(c4ccccc4C)c4cc(-c5ccccc5)cc1c43)C(C)(C)CCC2(C)C ; Cc1ccccc1N1c2cc3oc4ccccc4c3cc2B2c3cc(C(C)(C)C)ccc3N(c3cc4c(cc3C)C(C)(C)CCC4(C)C)c3cc(-c4ccccc4)cc1c32]

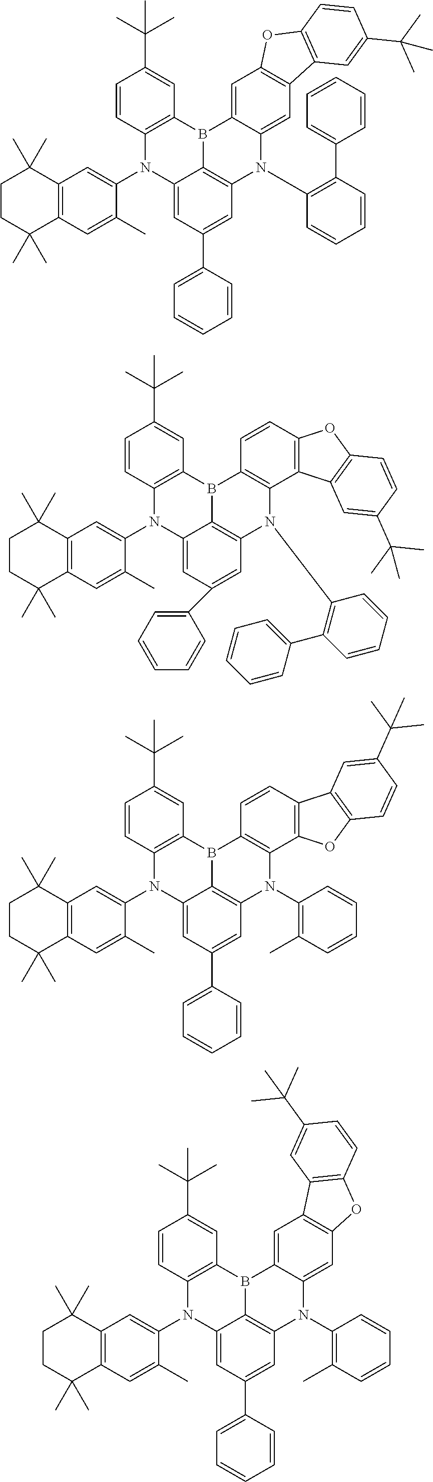

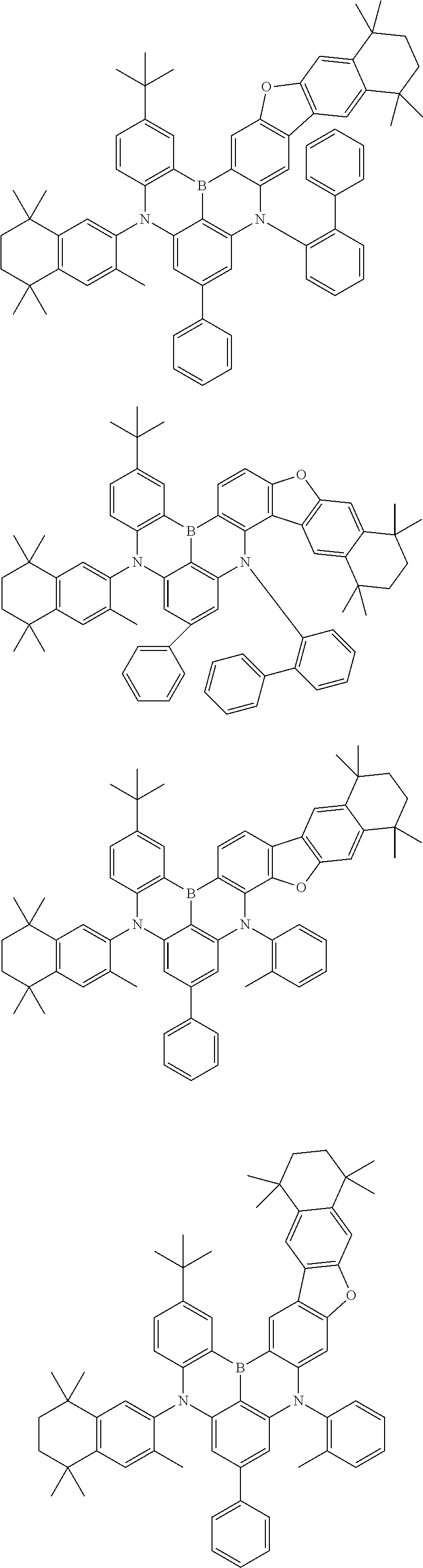

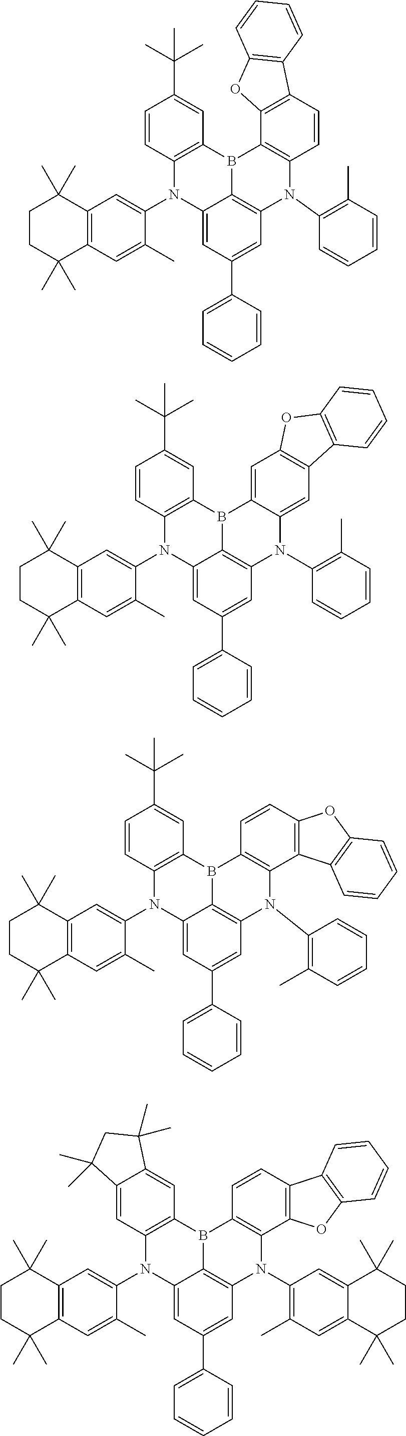 [SMILES: Cc1cc2c(cc1N1c3ccc(C(C)(C)C)cc3B3c4c1cc(-c1ccccc1)cc4N(c1ccccc1C)c1ccc4c(oc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5ccccc5)cc1c42)oc1ccccc13 ; Cc1cc2c(cc1N1c3ccc(C(C)(C)C)cc3B3c4ccc5oc6ccccc6c5c4N(c4ccccc4C)c4cc(-c5ccccc5)cc1c43)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(-c6ccccc6)cc1c53)C(C)(C)CC4(C)C)C(C)(C)CCC2(C)C]

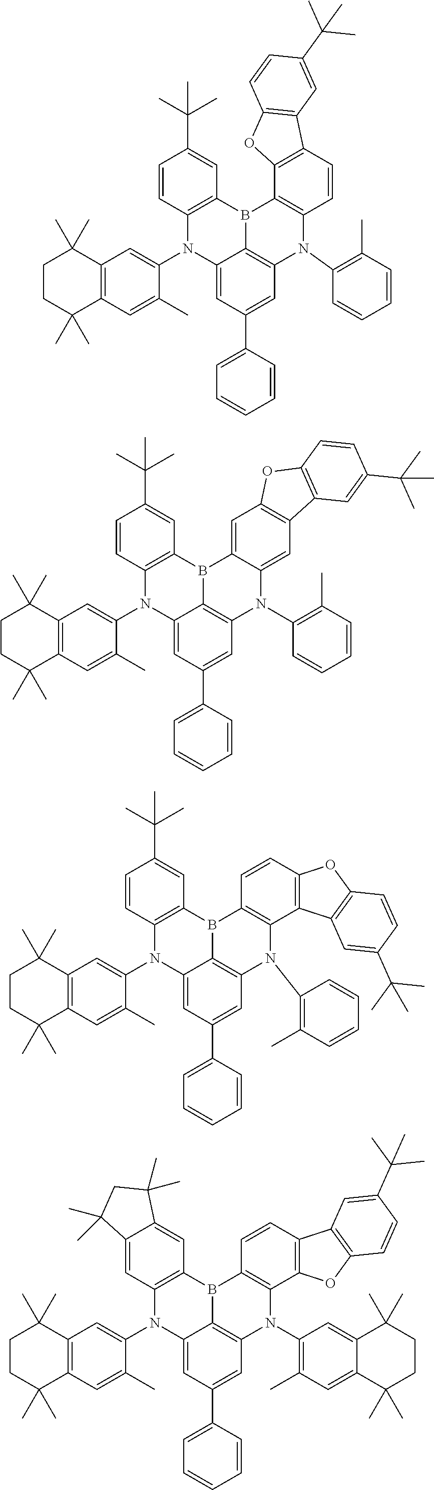

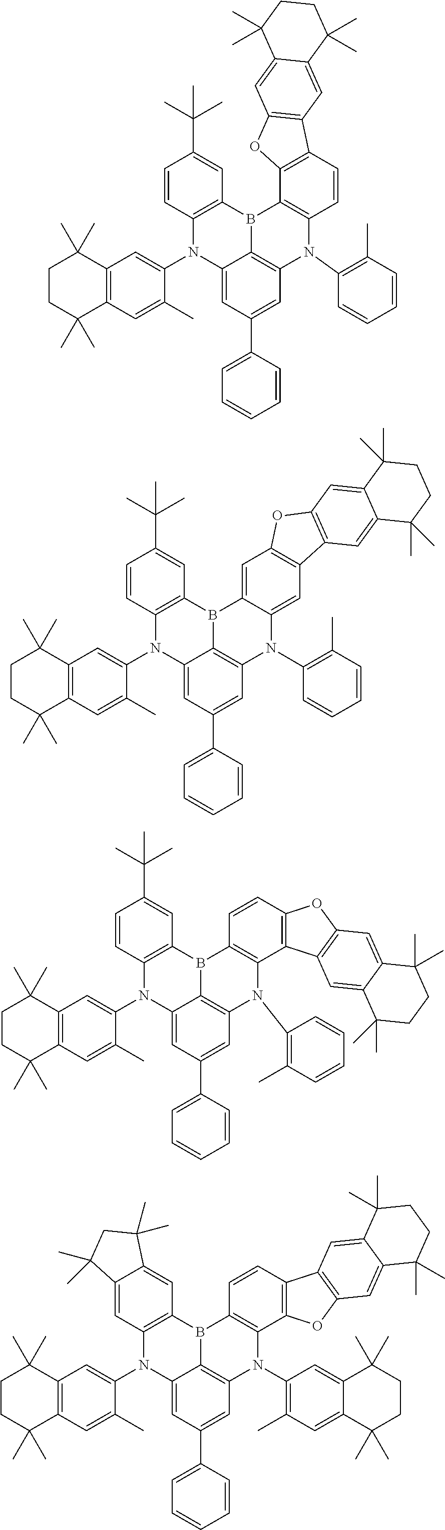

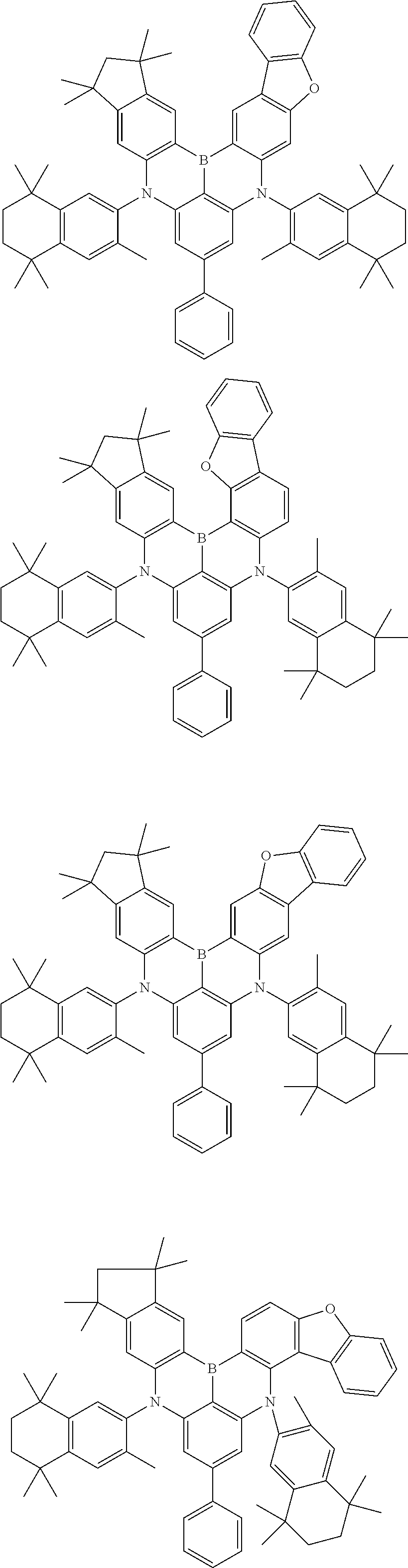

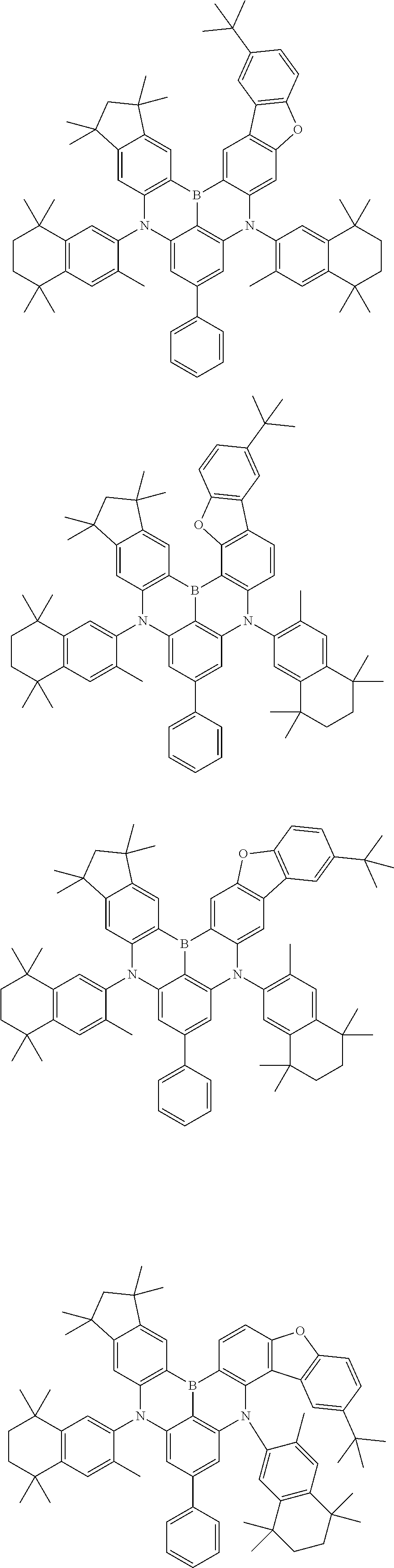

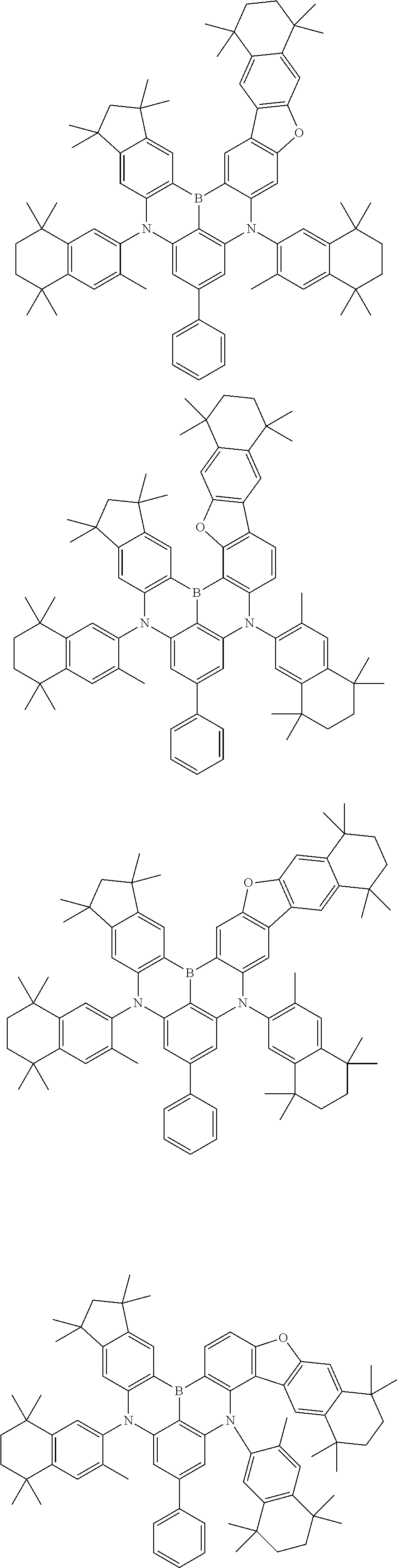

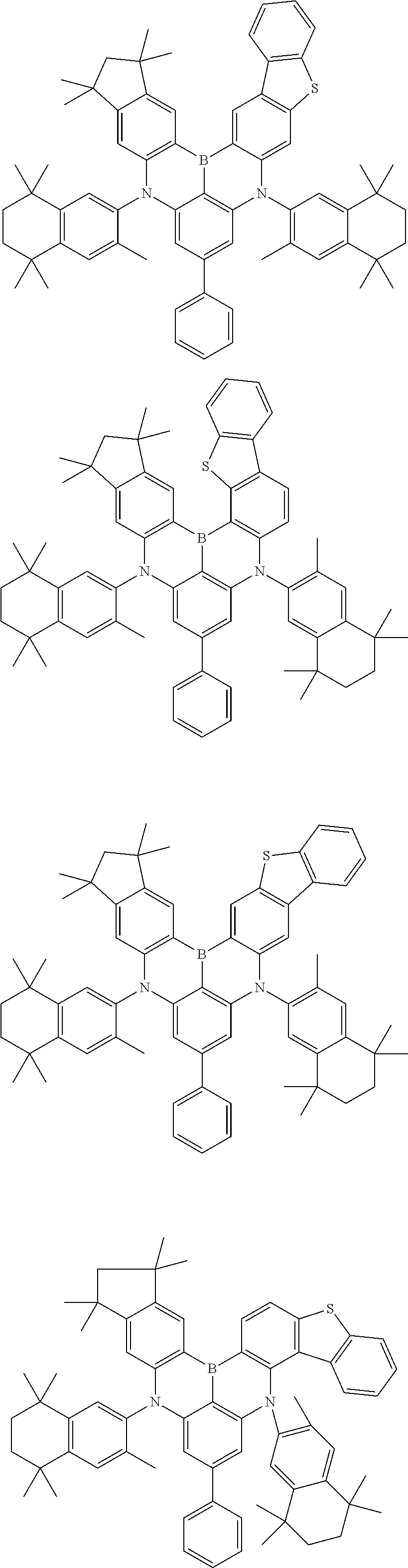

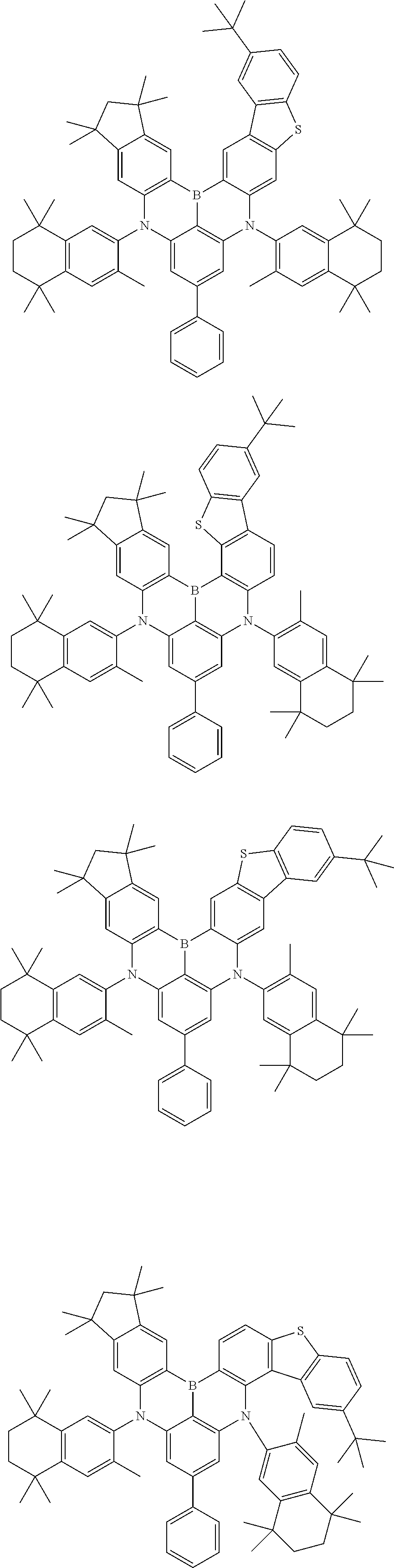

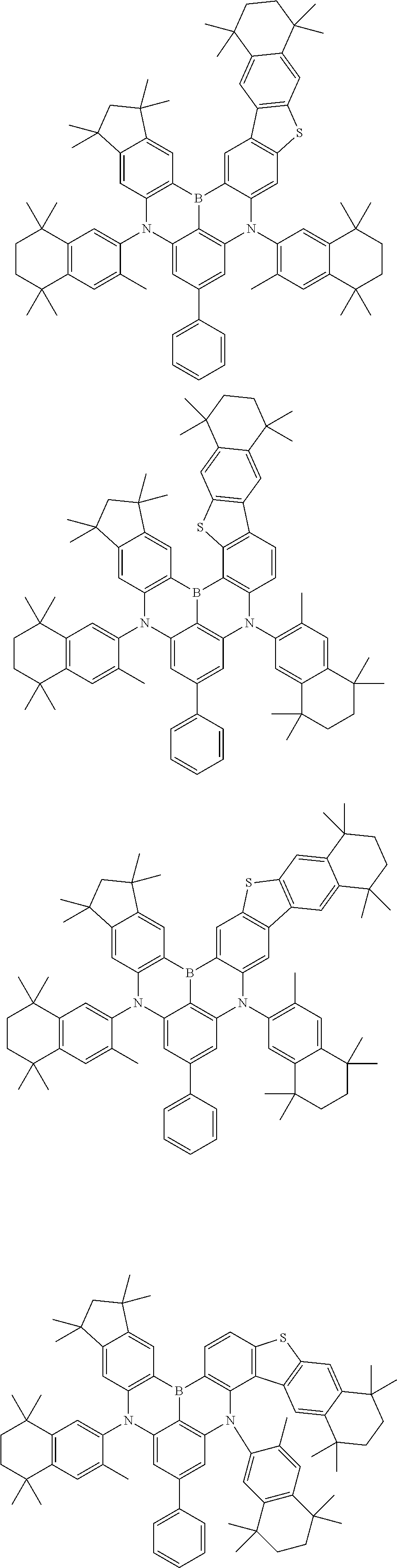

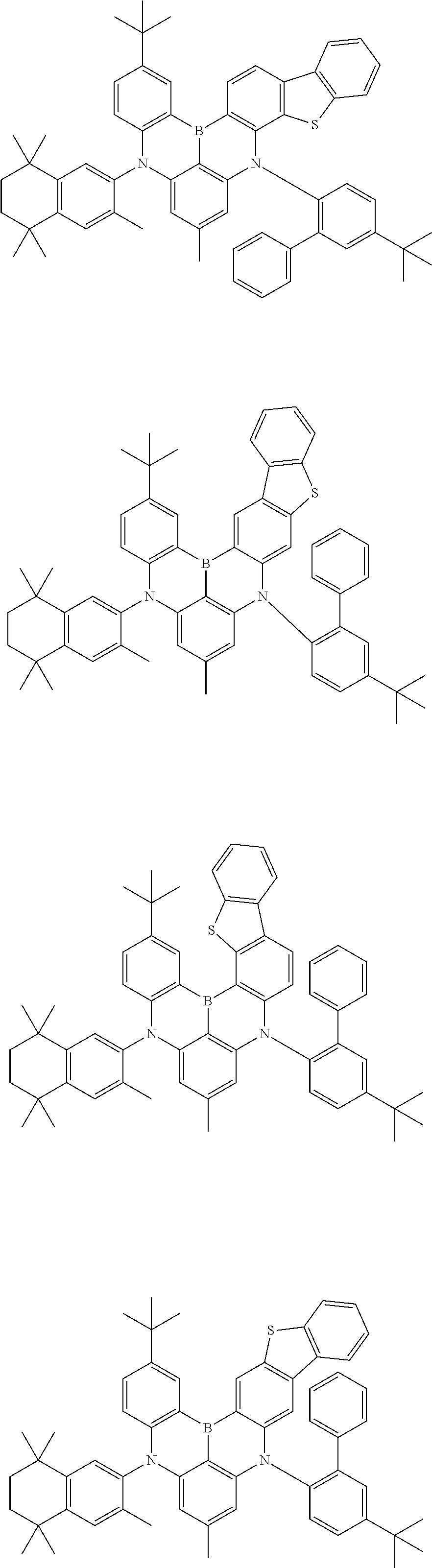 [SMILES: Cc1cc2c3c(c1)N(c1ccc(C(C)(C)C)cc1-c1ccccc1)c1c(ccc4c1sc1ccccc14)B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1cc4sc5ccccc5c4cc1B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1ccc4c(sc5ccccc54)c1B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)sc1ccccc14]

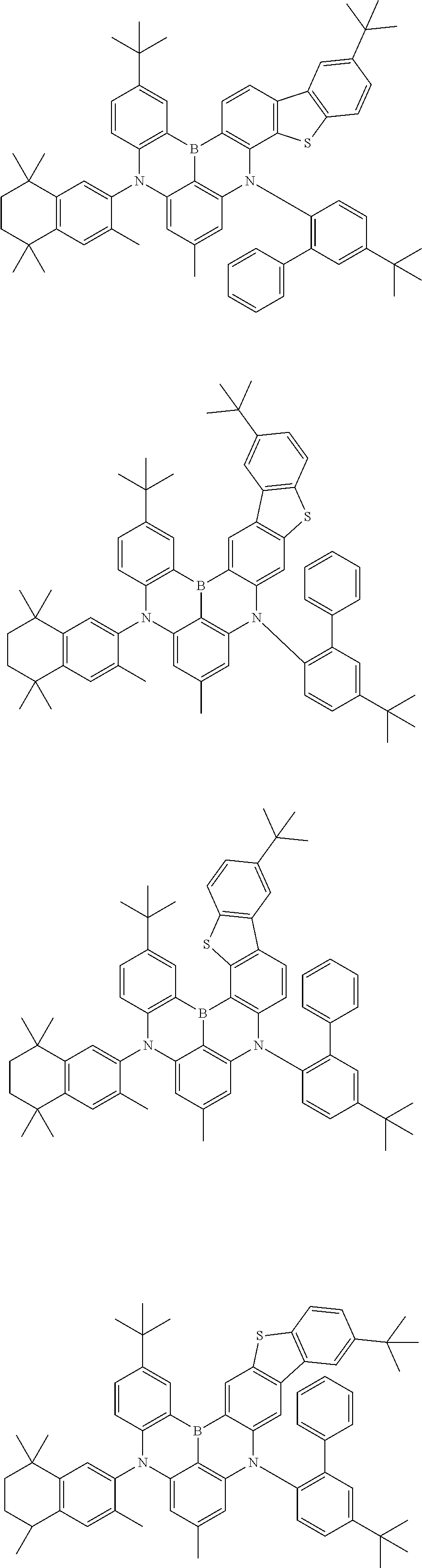 [SMILES: Cc1cc2c3c(c1)N(c1ccc(C(C)(C)C)cc1-c1ccccc1)c1c(ccc4c1sc1ccc(C(C)(C)C)cc14)B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1cc4sc5ccc(C(C)(C)C)cc5c4cc1B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1ccc4c(sc5ccc(C(C)(C)C)cc54)c1B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1cc(C(C)(C)C)ccc1N2c1cc2c(cc1C)C(C)CCC2(C)C)sc1ccc(C(C)(C)C)cc14]

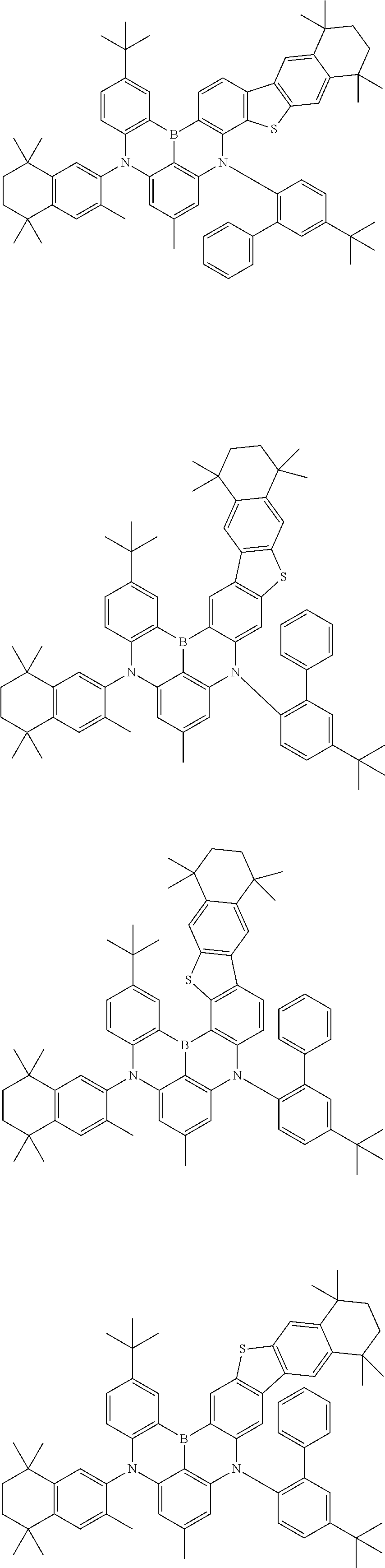

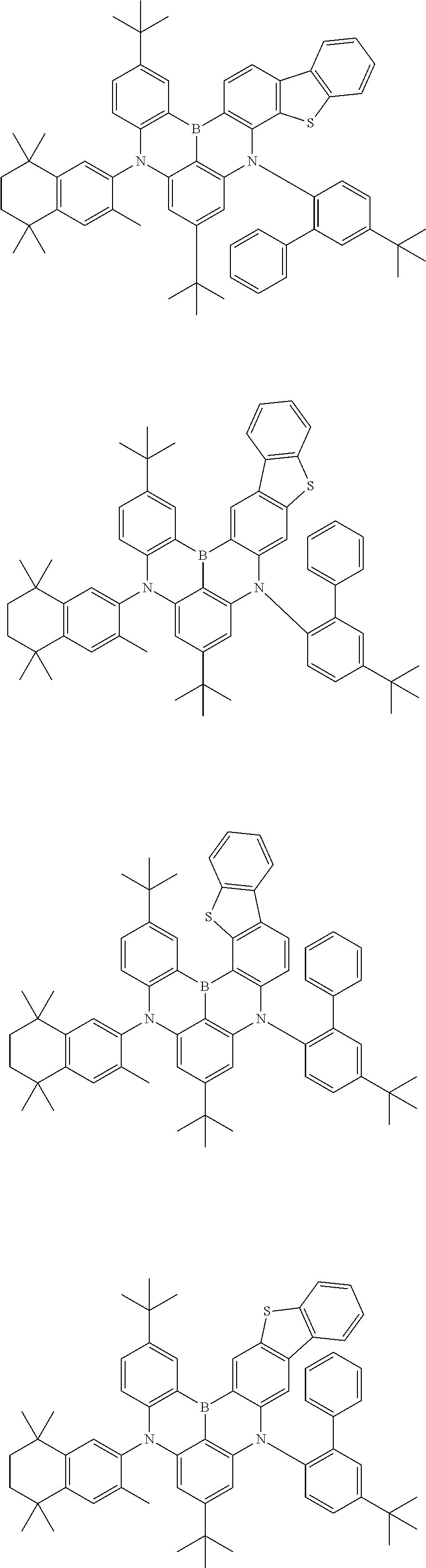 [SMILES: Cc1cc2c(cc1N1c3ccc(C(C)(C)C)cc3B3c4ccc5c(sc6ccccc65)c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(C(C)(C)C)cc1c43)sc1ccccc15)C(C)(C)CCC2(C)C ; Cc1cc2c(cc1N1c3ccc(C(C)(C)C)cc3B3c4c1cc(C(C)(C)C)cc4N(c1ccc(C(C)(C)C)cc1-c1ccccc1)c1ccc4c(sc5ccccc54)c13)C(C)(C)CCC2(C)C ; Cc1cc2c(cc1N1c3ccc(C(C)(C)C)cc3B3c4cc5sc6ccccc6c5cc4N(c4ccc(C(C)(C)C)cc4-c4ccccc4)c4cc(C(C)(C)C)cc1c43)C(C)(C)CCC2(C)C]

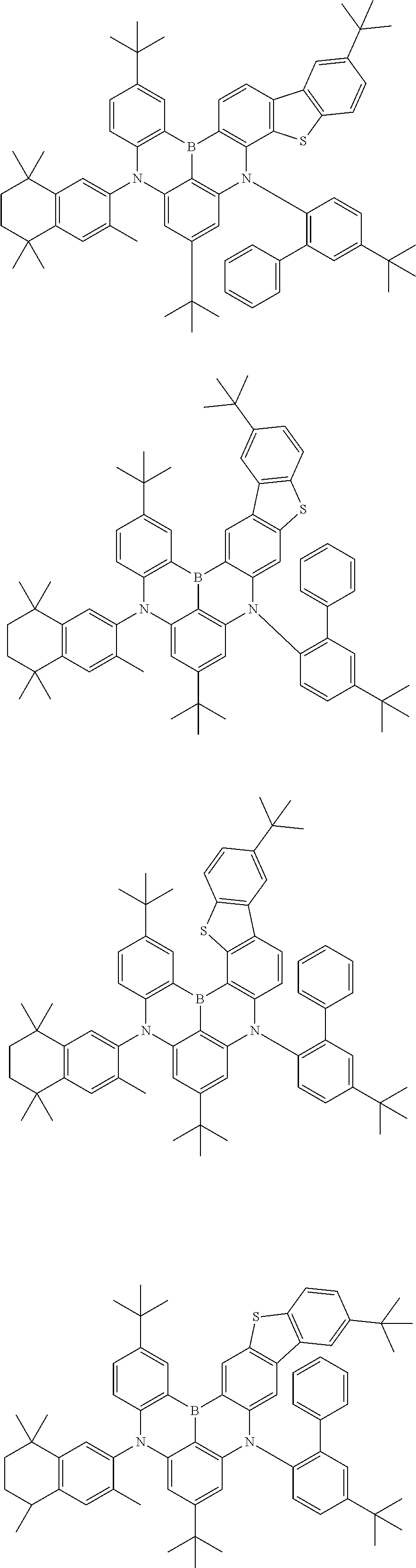

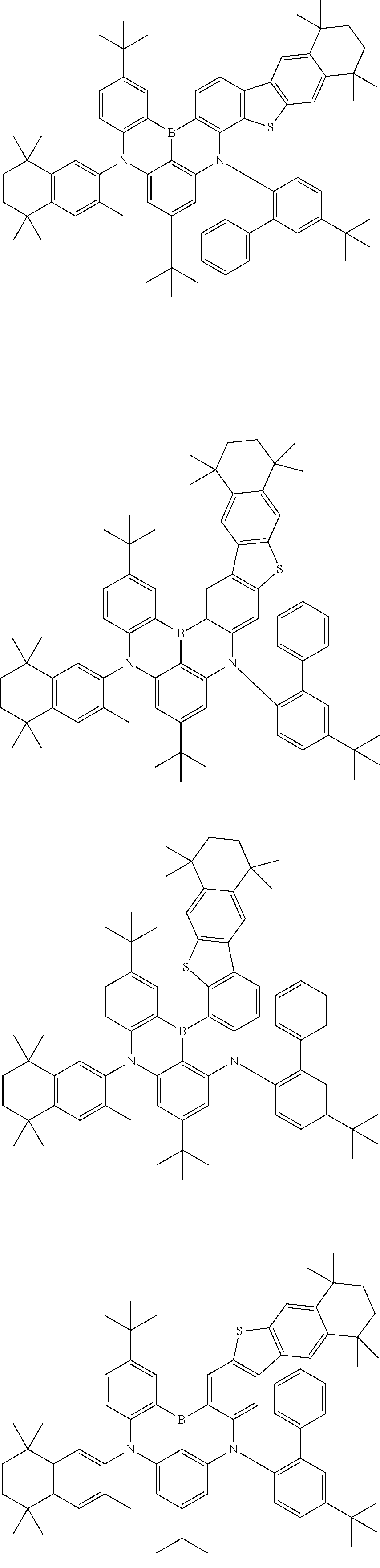

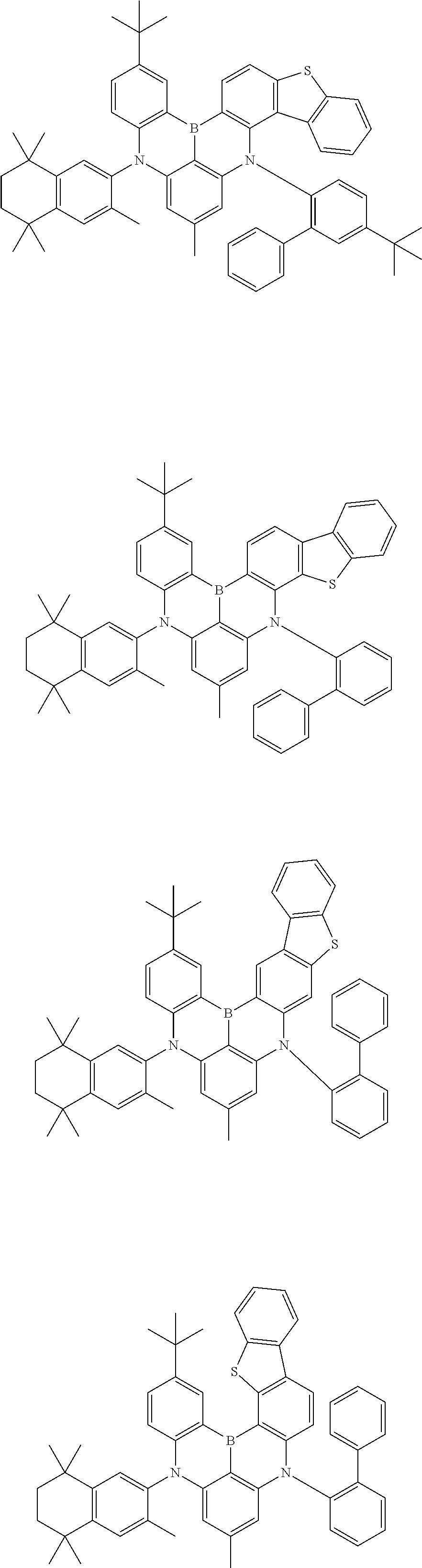 [SMILES: Cc1cc2c3c(c1)N(c1ccc(C(C)(C)C)cc1-c1ccccc1)c1c(ccc4sc5ccccc5c14)B3c1cc(C(C)(C)C)ccc1N2c1cc2c(cc1C)C(C)(C)CCC2(C)C ; Cc1cc2c3c(c1)N(c1ccccc1-c1ccccc1)c1c(ccc4c1sc1ccccc14)B3c1cc(C(C)(C)C)ccc1N2c1cc2c(cc1C)C(C)(C)CCC2(C)C ; Cc1cc2c3c(c1)N(c1ccccc1-c1ccccc1)c1cc4sc5ccccc5c4cc1B3c1cc(C(C)(C)C)ccc1N2c1cc2c(cc1C)C(C)(C)CCC2(C)C ; Cc1cc2c3c(c1)N(c1ccccc1-c1ccccc1)c1ccc4c(sc5ccccc54)c1B3c1cc(C(C)(C)C)ccc1N2c1cc2c(cc1C)C(C)(C)CCC2(C)C]

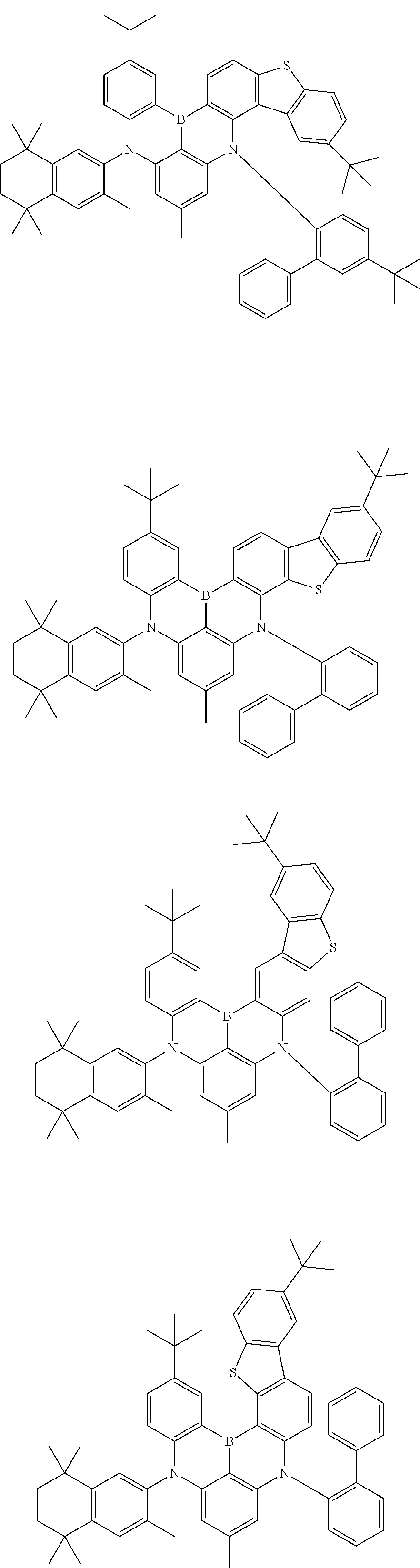

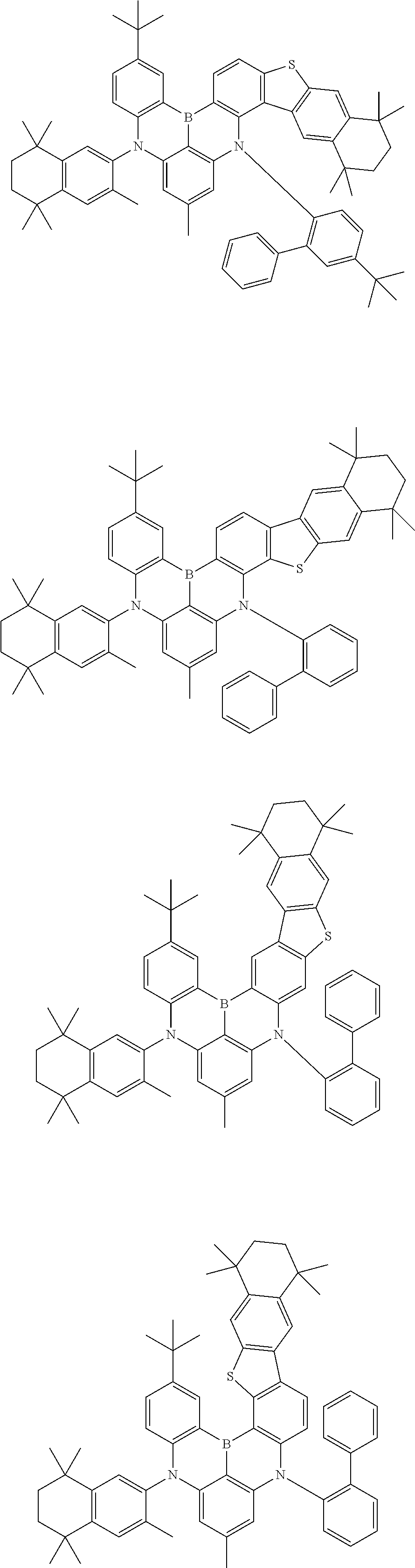

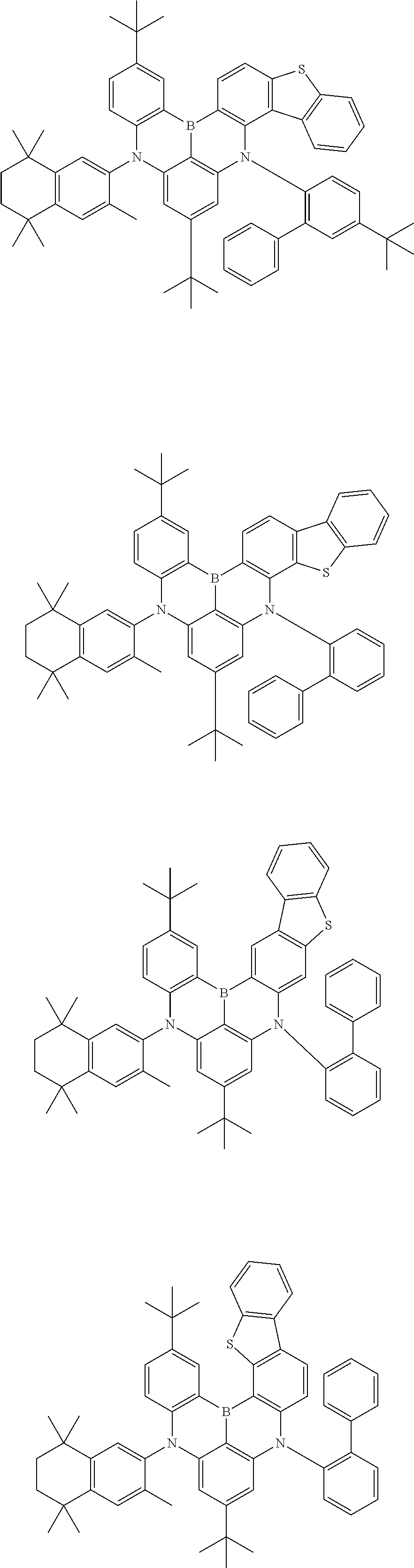 [SMILES: Cc1cc2c(cc1N1c3ccc(C(C)(C)C)cc3B3c4ccc5sc6ccccc6c5c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccccc65)c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(C(C)(C)C)cc1c43)sc1ccccc15)C(C)(C)CCC2(C)C ; Cc1cc2c(cc1N1c3ccc(C(C)(C)C)cc3B3c4c1cc(C(C)(C)C)cc4N(c1ccccc1-c1ccccc1)c1ccc4c(sc5ccccc54)c13)C(C)(C)CCC2(C)C]

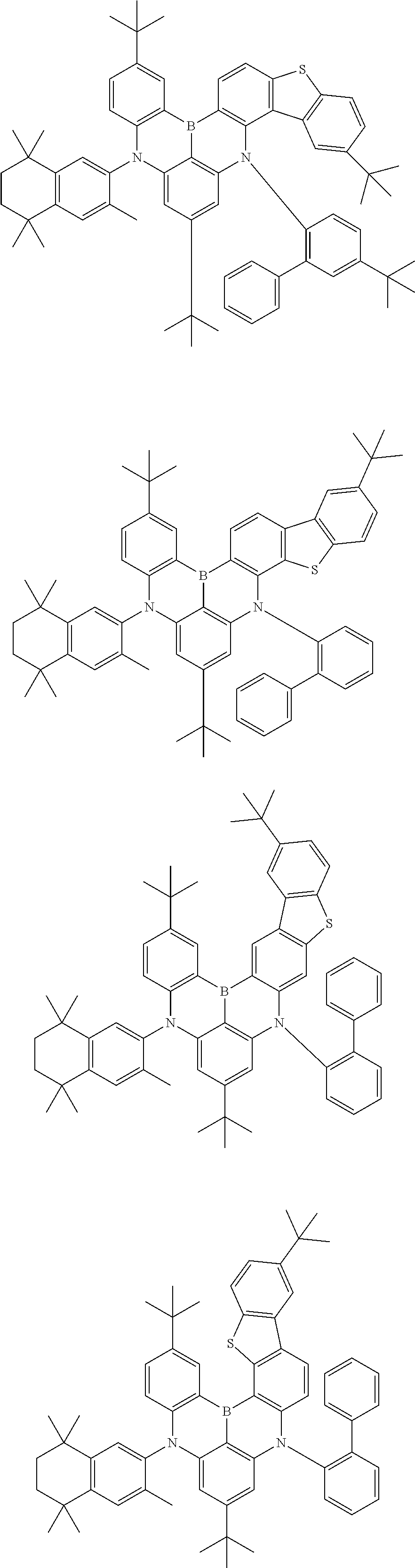 [SMILES: Cc1cc2c(cc1N1c3ccc(C(C)(C)C)cc3B3c4ccc5sc6ccc(C(C)(C)C)cc6c5c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(C(C)(C)C)cc1c43)sc1ccc(C(C)(C)C)cc15)C(C)(C)CCC2(C)C ; Cc1cc2c(cc1N1c3ccc(C(C)(C)C)cc3B3c4c1cc(C(C)(C)C)cc4N(c1ccccc1-c1ccccc1)c1ccc4c(sc5ccc(C(C)(C)C)cc54)c13)C(C)(C)CCC2(C)C]

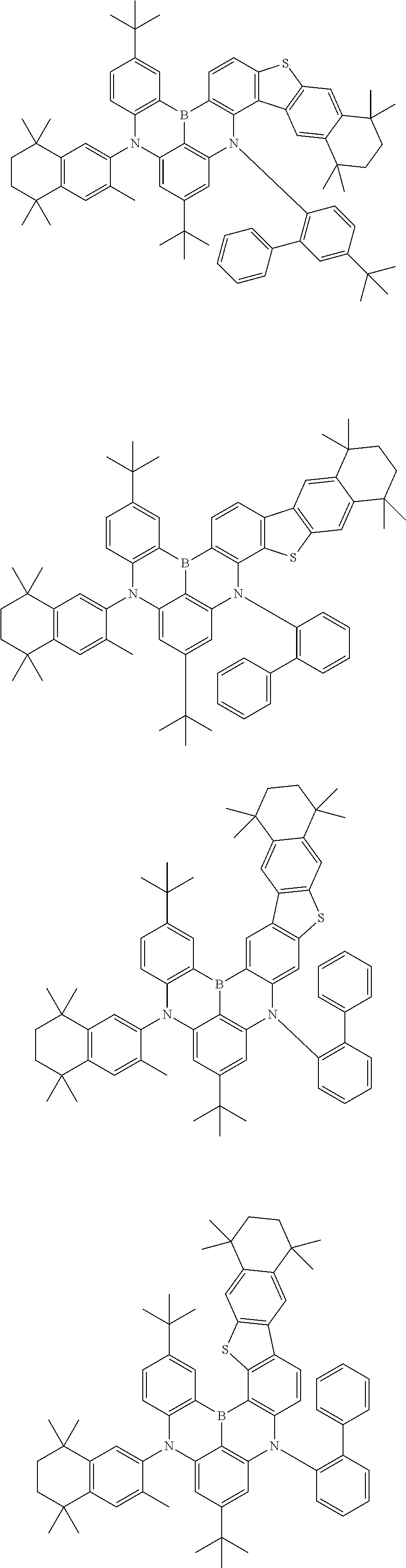

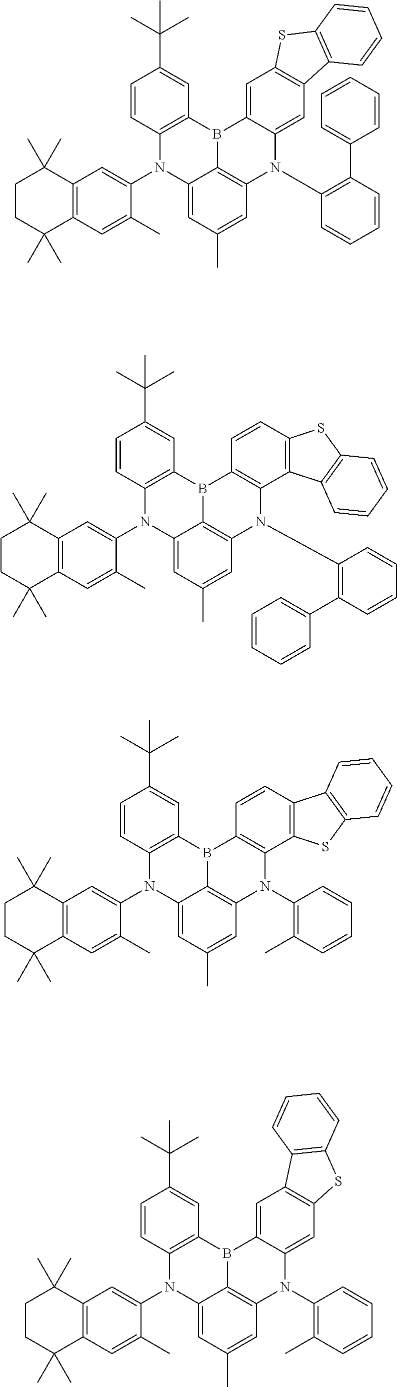 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1ccccc14 ; Cc1cc2c3c(c1)N(c1ccccc1-c1ccccc1)c1c(ccc4sc5ccccc5c14)B3c1cc(C(C)(C)C)ccc1N2c1cc2c(cc1C)C(C)(C)CCC2(C)C ; Cc1cc2c3c(c1)N(c1ccccc1C)c1c(ccc4c1sc1ccccc14)B3c1cc(C(C)(C)C)ccc1N2c1cc2c(cc1C)C(C)(C)CCC2(C)C ; Cc1cc2c3c(c1)N(c1ccccc1C)c1cc4sc5ccccc5c4cc1B3c1cc(C(C)(C)C)ccc1N2c1cc2c(cc1C)C(C)(C)CCC2(C)C]

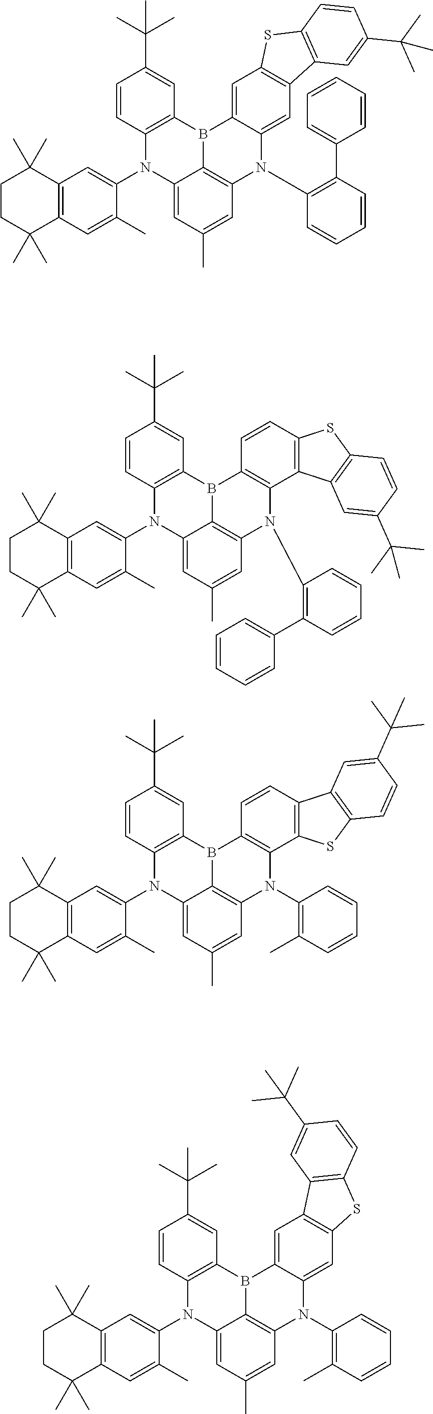 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1ccc(C(C)(C)C)cc14 ; Cc1cc2c3c(c1)N(c1ccccc1-c1ccccc1)c1c(ccc4sc5ccc(C(C)(C)C)cc5c14)B3c1cc(C(C)(C)C)ccc1N2c1cc2c(cc1C)C(C)(C)CCC2(C)C ; Cc1cc2c3c(c1)N(c1ccccc1C)c1c(ccc4c1sc1ccc(C(C)(C)C)cc14)B3c1cc(C(C)(C)C)ccc1N2c1cc2c(cc1C)C(C)(C)CCC2(C)C ; Cc1cc2c3c(c1)N(c1ccccc1C)c1cc4sc5ccc(C(C)(C)C)cc5c4cc1B3c1cc(C(C)(C)C)ccc1N2c1cc2c(cc1C)C(C)(C)CCC2(C)C]

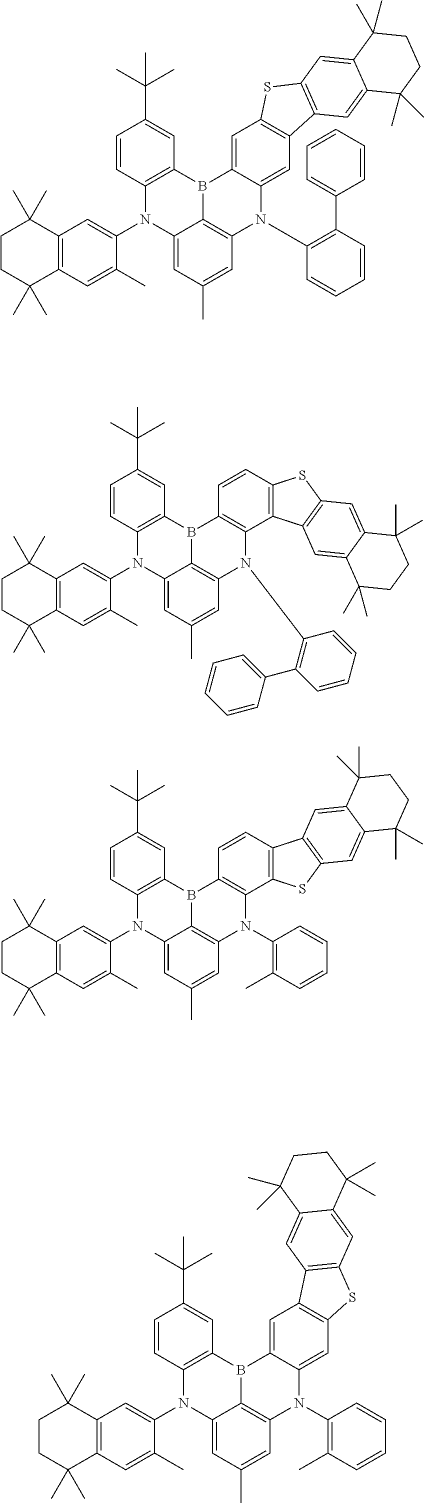 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1cc2c3c(c1)N(c1ccccc1-c1ccccc1)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1cc2c3c(c1)N(c1ccccc1C)c1c(ccc4c1sc1cc5c(cc14)C(C)(C)CCC5(C)C)B3c1cc(C(C)(C)C)ccc1N2c1cc2c(cc1C)C(C)(C)CCC2(C)C ; Cc1cc2c3c(c1)N(c1ccccc1C)c1cc4sc5cc6c(cc5c4cc1B3c1cc(C(C)(C)C)ccc1N2c1cc2c(cc1C)C(C)(C)CCC2(C)C)C(C)(C)CCC6(C)C]

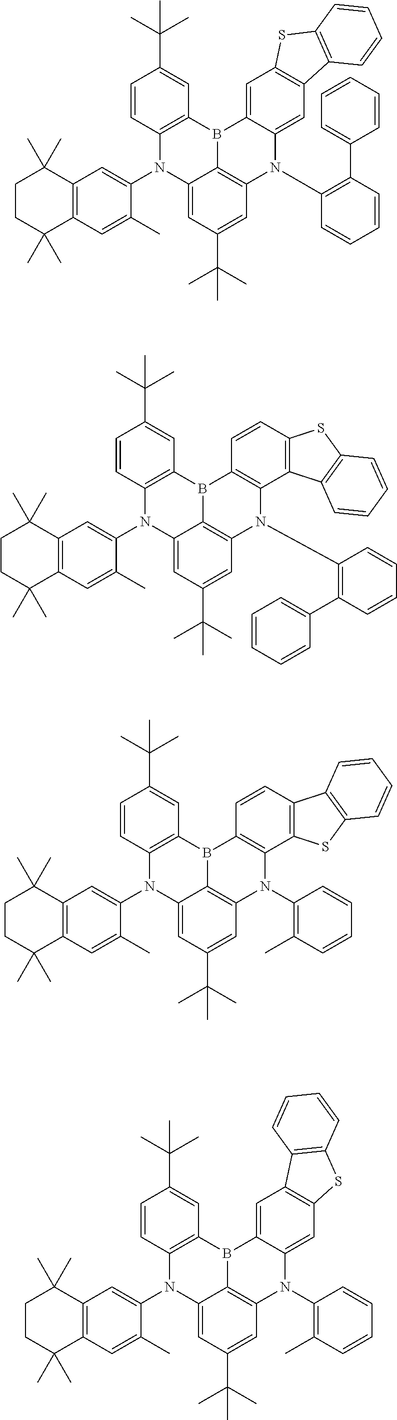 [SMILES: Cc1cc2c(cc1N1c3ccc(C(C)(C)C)cc3B3c4cc5sc6ccccc6c5cc4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5sc6ccccc6c5c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccccc65)c4N(c4ccccc4C)c4cc(C(C)(C)C)cc1c43)C(C)(C)CCC2(C)C ; Cc1ccccc1N1c2cc3sc4ccccc4c3cc2B2c3cc(C(C)(C)C)ccc3N(c3cc4c(cc3C)C(C)(C)CCC4(C)C)c3cc(C(C)(C)C)cc1c32]

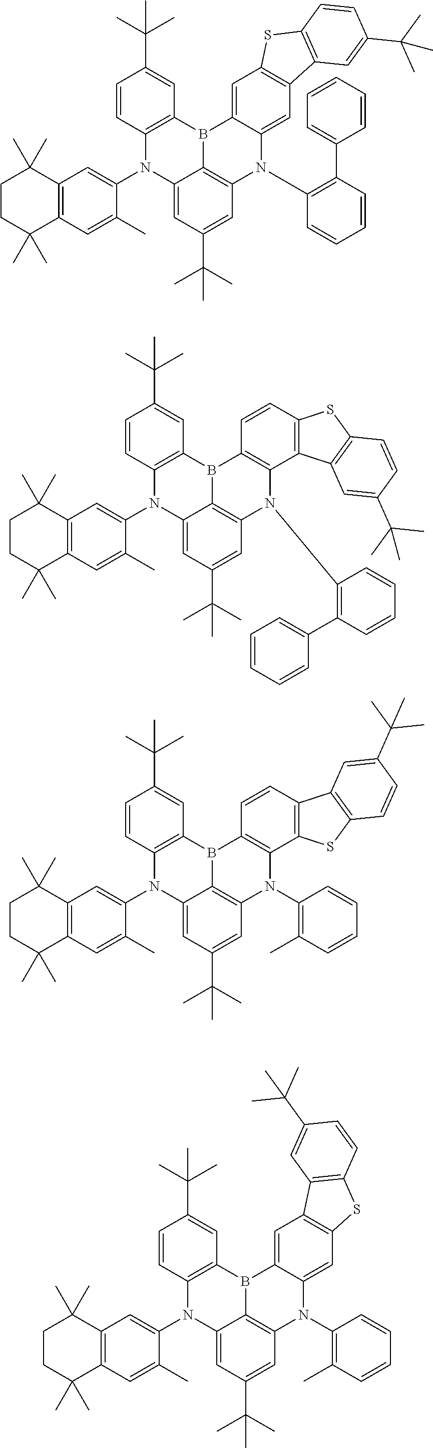 [SMILES: Cc1cc2c(cc1N1c3ccc(C(C)(C)C)cc3B3c4cc5sc6ccc(C(C)(C)C)cc6c5cc4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5sc6ccc(C(C)(C)C)cc6c5c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4C)c4cc(C(C)(C)C)cc1c43)C(C)(C)CCC2(C)C ; Cc1ccccc1N1c2cc3sc4ccc(C(C)(C)C)cc4c3cc2B2c3cc(C(C)(C)C)ccc3N(c3cc4c(cc3C)C(C)(C)CCC4(C)C)c3cc(C(C)(C)C)cc1c32]

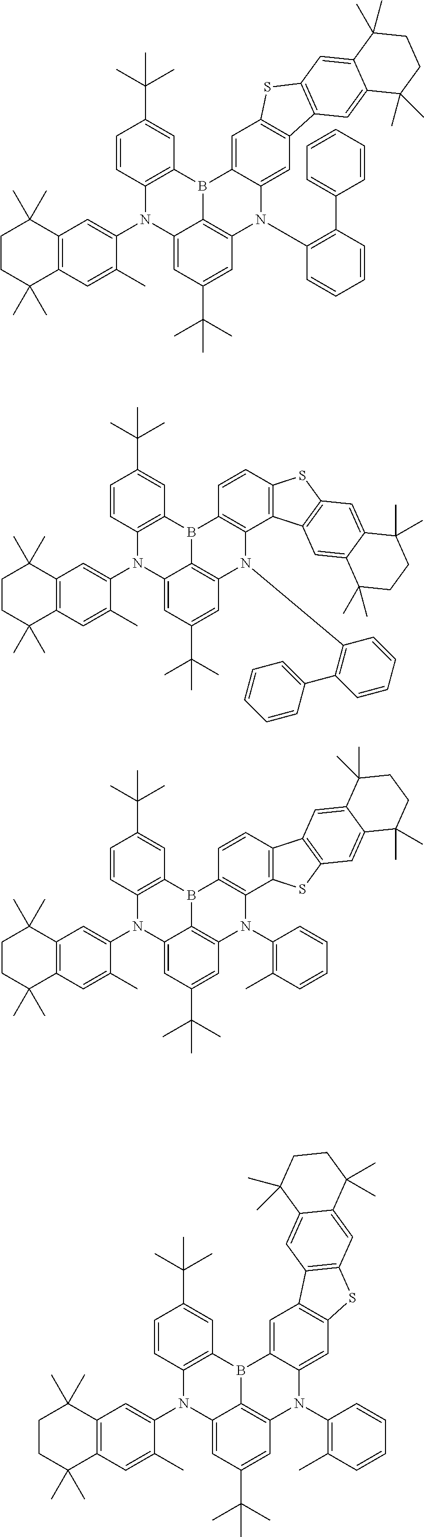 [SMILES: Cc1cc2c(cc1N1c3ccc(C(C)(C)C)cc3B3c4cc5sc6cc7c(cc6c5cc4N(c4ccccc4-c4ccccc4)c4cc(C(C)(C)C)cc1c43)C(C)(C)CCC7(C)C)C(C)(C)CCC2(C)C ; Cc1cc2c(cc1N1c3ccc(C(C)(C)C)cc3B3c4ccc5sc6cc7c(cc6c5c4N(c4ccccc4-c4ccccc4)c4cc(C(C)(C)C)cc1c43)C(C)(C)CCC7(C)C)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccccc4C)c4cc(C(C)(C)C)cc1c43)C(C)(C)CCC2(C)C ; Cc1ccccc1N1c2cc3sc4cc5c(cc4c3cc2B2c3cc(C(C)(C)C)ccc3N(c3cc4c(cc3C)C(C)(C)CCC4(C)C)c3cc(C(C)(C)C)cc1c32)C(C)(C)CCC5(C)C]

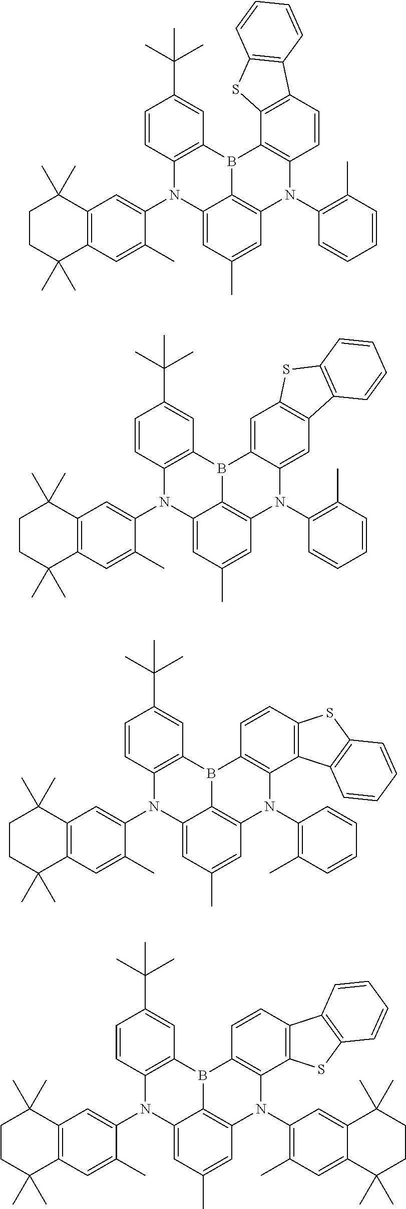 [SMILES: Cc1cc2c3c(c1)N(c1ccccc1C)c1ccc4c(sc5ccccc54)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)sc1ccccc14 ; Cc1cc2c3c(c1)N(c1ccccc1C)c1c(ccc4sc5ccccc5c14)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1sc1ccccc14)B3c1cc(C(C)(C)C)ccc1N2c1cc2c(cc1C)C(C)(C)CCC2(C)C]

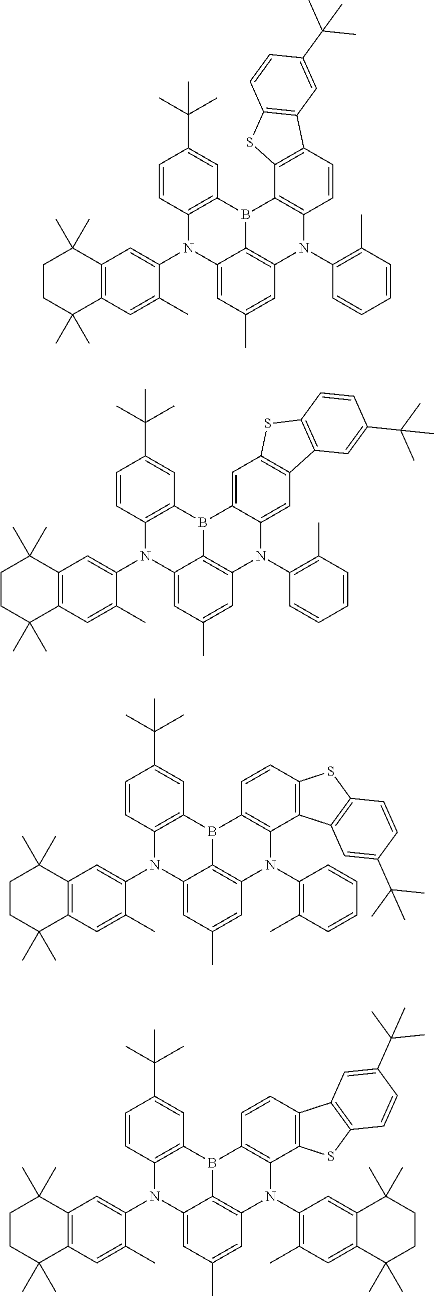 [SMILES: Cc1cc2c3c(c1)N(c1ccccc1C)c1ccc4c(sc5ccc(C(C)(C)C)cc54)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)sc1ccc(C(C)(C)C)cc14 ; Cc1cc2c3c(c1)N(c1ccccc1C)c1c(ccc4sc5ccc(C(C)(C)C)cc5c14)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1sc1ccc(C(C)(C)C)cc14)B3c1cc(C(C)(C)C)ccc1N2c1cc2c(cc1C)C(C)(C)CCC2(C)C]

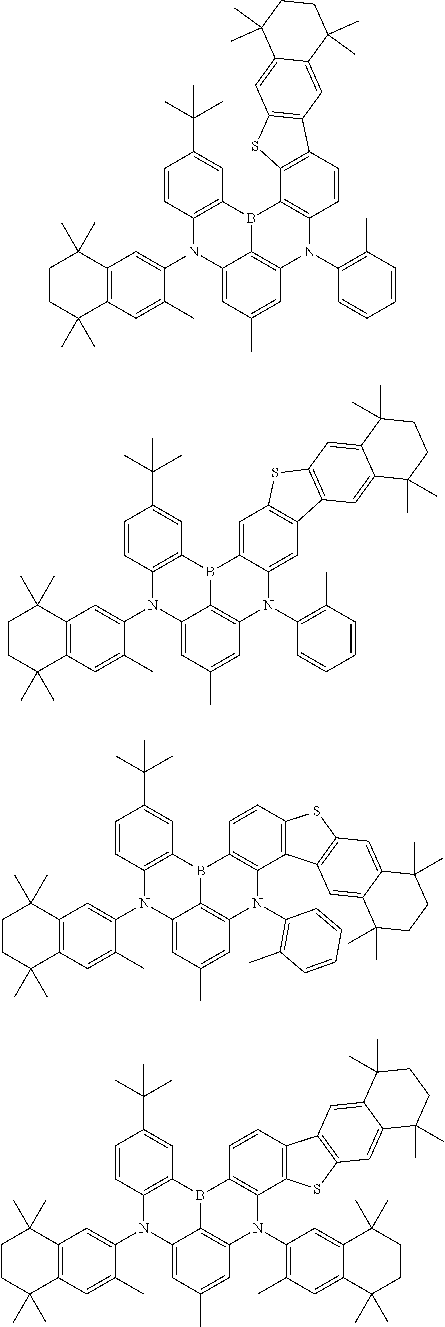 [SMILES: Cc1cc2c3c(c1)N(c1ccccc1C)c1ccc4c(sc5cc6c(cc54)C(C)(C)CCC6(C)C)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1cc2c3c(c1)N(c1ccccc1C)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1sc1cc5c(cc14)C(C)(C)CCC5(C)C)B3c1cc(C(C)(C)C)ccc1N2c1cc2c(cc1C)C(C)(C)CCC2(C)C]

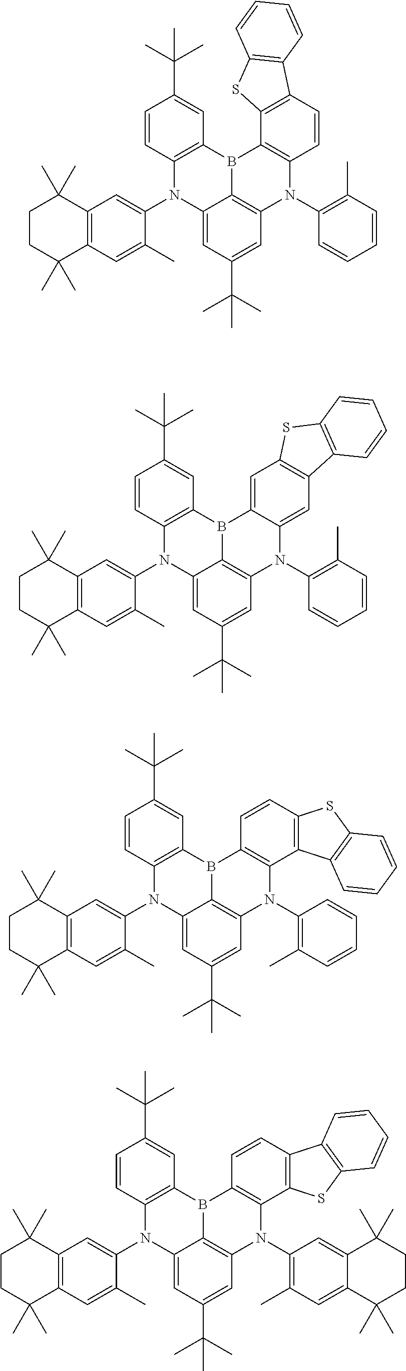 [SMILES: Cc1cc2c(cc1N1c3ccc(C(C)(C)C)cc3B3c4c1cc(C(C)(C)C)cc4N(c1ccccc1C)c1ccc4c(sc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(C(C)(C)C)cc1c42)sc1ccccc13 ; Cc1cc2c(cc1N1c3ccc(C(C)(C)C)cc3B3c4ccc5sc6ccccc6c5c4N(c4ccccc4C)c4cc(C(C)(C)C)cc1c43)C(C)(C)CCC2(C)C ; Cc1cc2c(cc1N1c3ccc(C(C)(C)C)cc3B3c4ccc5c(sc6ccccc65)c4N(c4cc5c(cc4C)C(C)(C)CCC5(C)C)c4cc(C(C)(C)C)cc1c43)C(C)(C)CCC2(C)C]

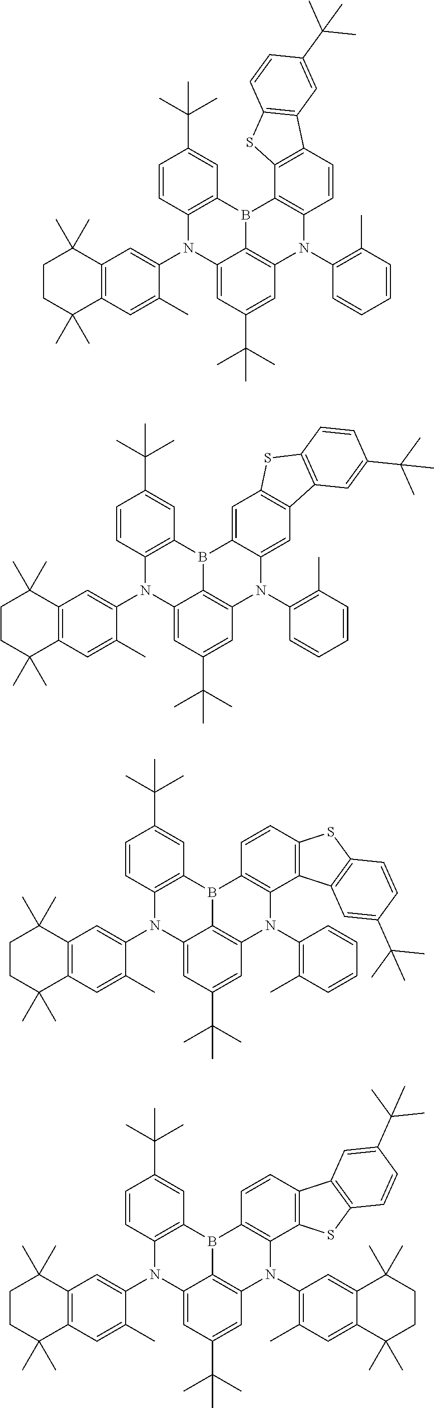 [SMILES: Cc1cc2c(cc1N1c3ccc(C(C)(C)C)cc3B3c4c1cc(C(C)(C)C)cc4N(c1ccccc1C)c1ccc4c(sc5ccc(C(C)(C)C)cc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(C(C)(C)C)cc1c42)sc1ccc(C(C)(C)C)cc13 ; Cc1cc2c(cc1N1c3ccc(C(C)(C)C)cc3B3c4ccc5sc6ccc(C(C)(C)C)cc6c5c4N(c4ccccc4C)c4cc(C(C)(C)C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4cc5c(cc4C)C(C)(C)CCC5(C)C)c4cc(C(C)(C)C)cc1c43)C(C)(C)CCC2(C)C]

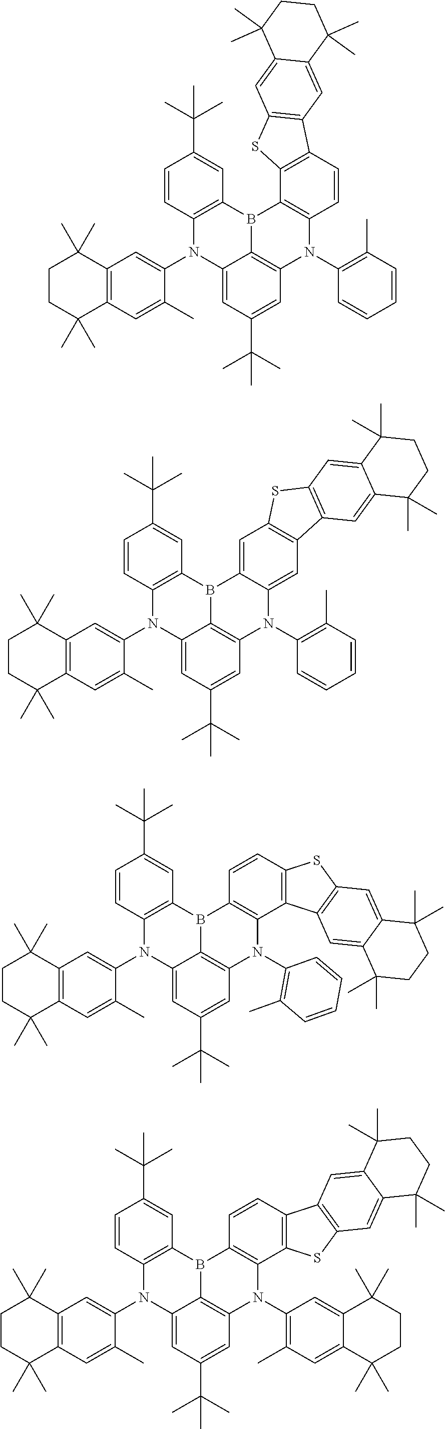

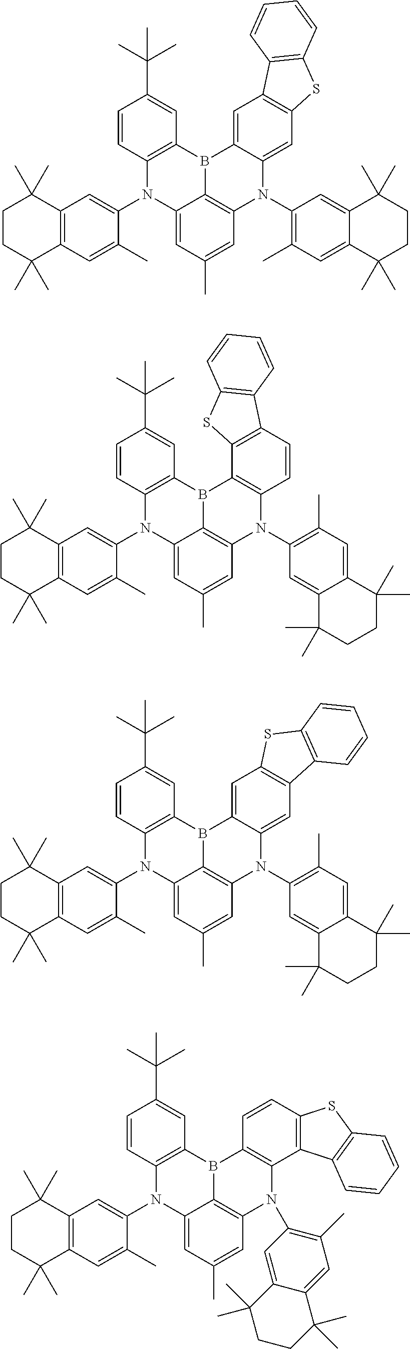

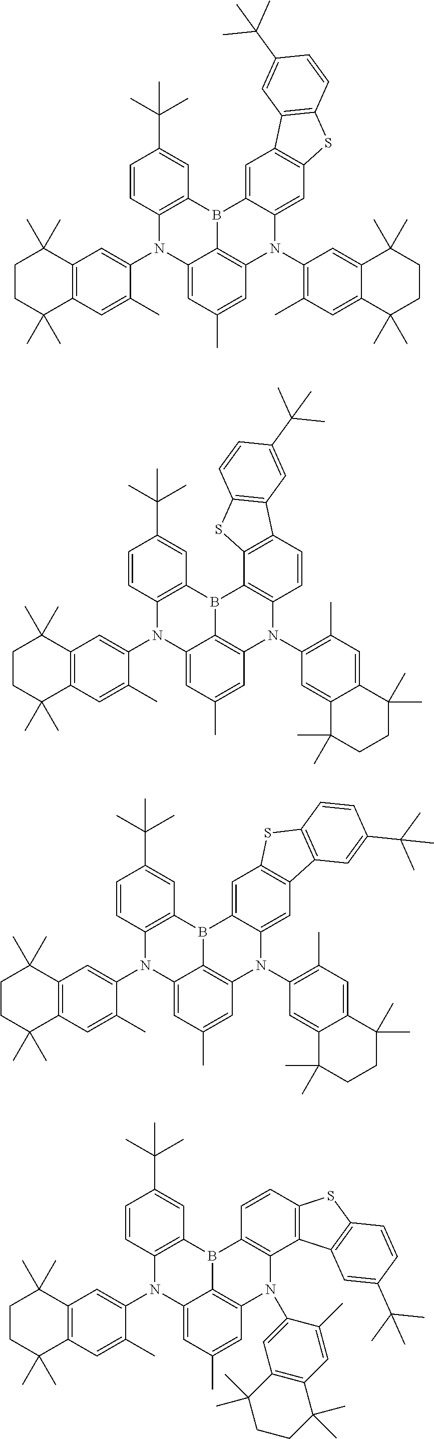

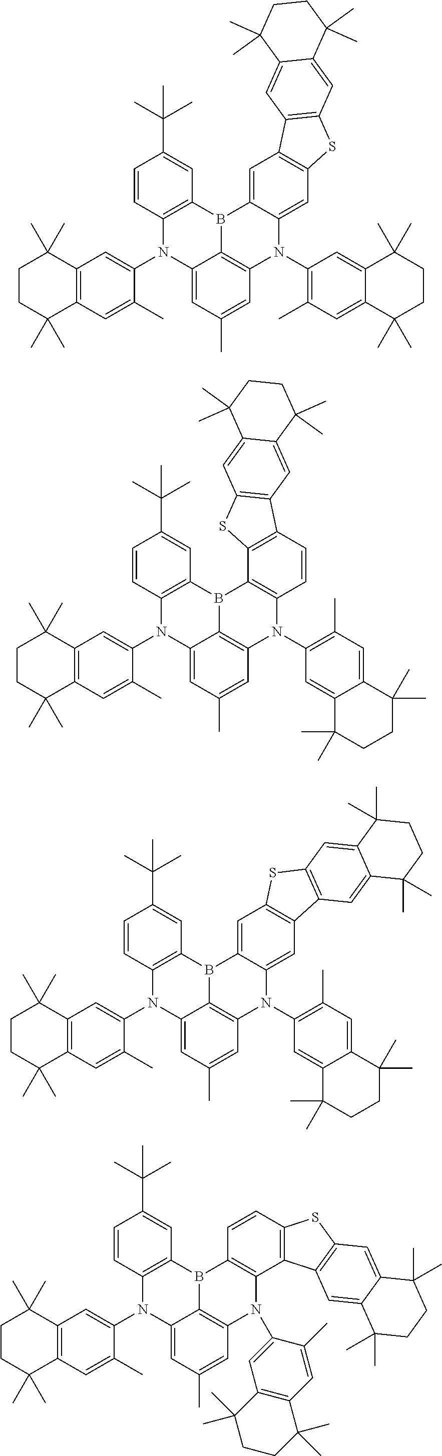

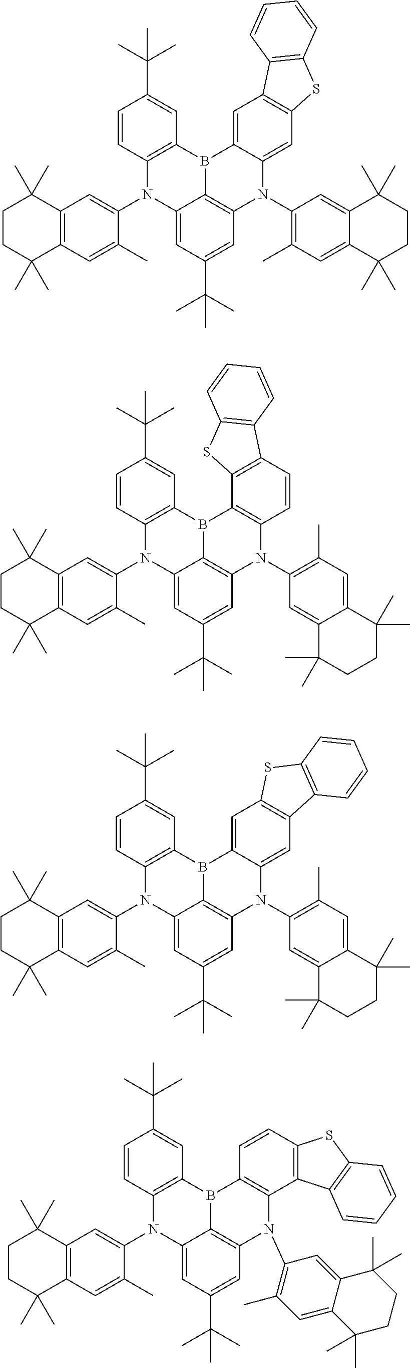

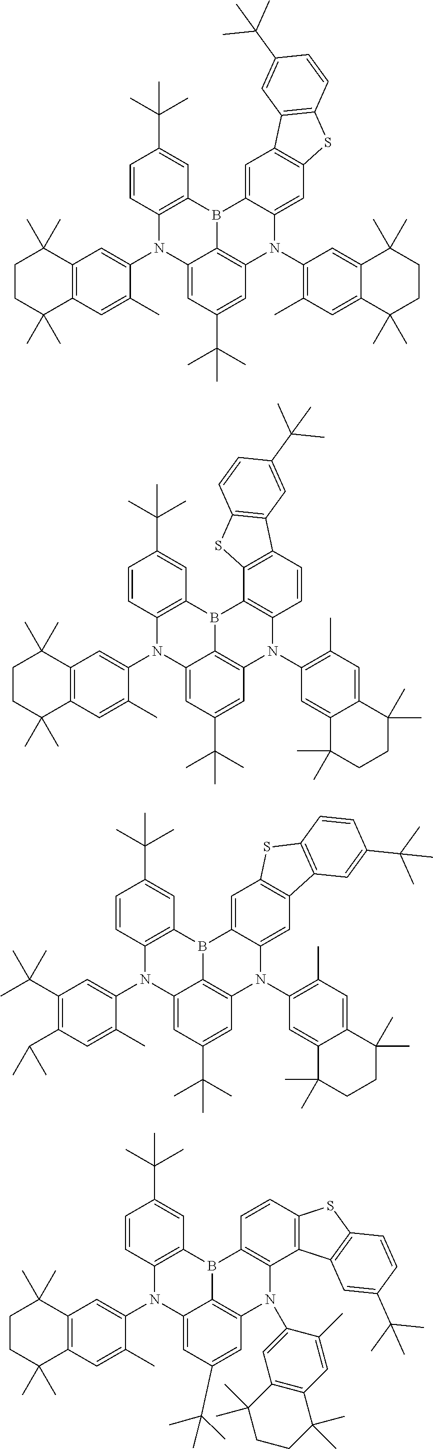

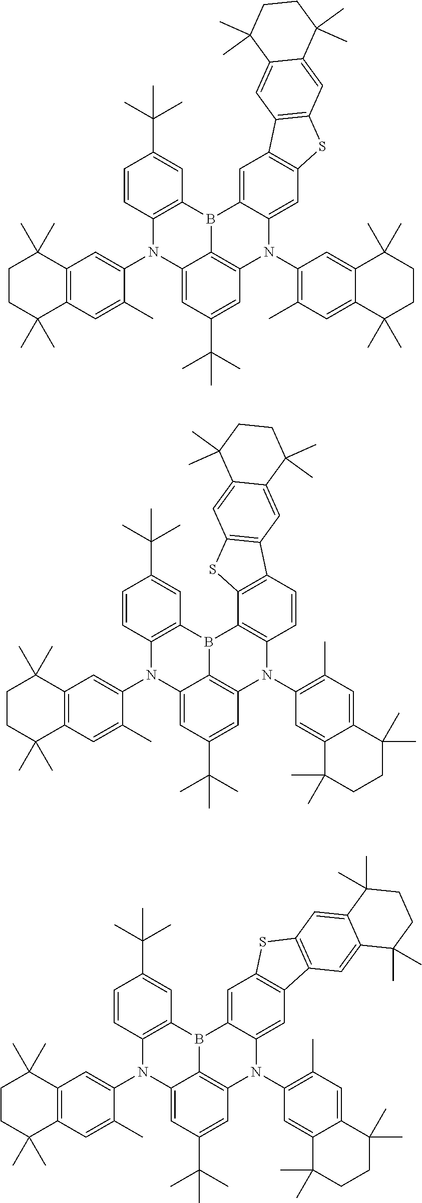 [SMILES: Cc1cc2c(cc1N1c3ccc(C(C)(C)C)cc3B3c4cc5c(cc4N(c4cc6c(cc4C)C(C)(C)CCC6(C)C)c4cc(C(C)(C)C)cc1c43)sc1cc3c(cc15)C(C)(C)CCC3(C)C)C(C)(C)CCC2(C)C ; Cc1cc2c(cc1N1c3ccc(C(C)(C)C)cc3B3c4c1cc(C(C)(C)C)cc4N(c1cc4c(cc1C)C(C)(C)CCC4(C)C)c1ccc4c(sc5cc6c(cc54)C(C)(C)CCC6(C)C)c13)C(C)(C)CCC2(C)C ; Cc1cc2c(cc1N1c3ccc(C(C)(C)C)cc3B3c4cc5sc6cc7c(cc6c5cc4N(c4cc5c(cc4C)C(C)(C)CCC5(C)C)c4cc(C(C)(C)C)cc1c43)C(C)(C)CCC7(C)C)C(C)(C)CCC2(C)C]

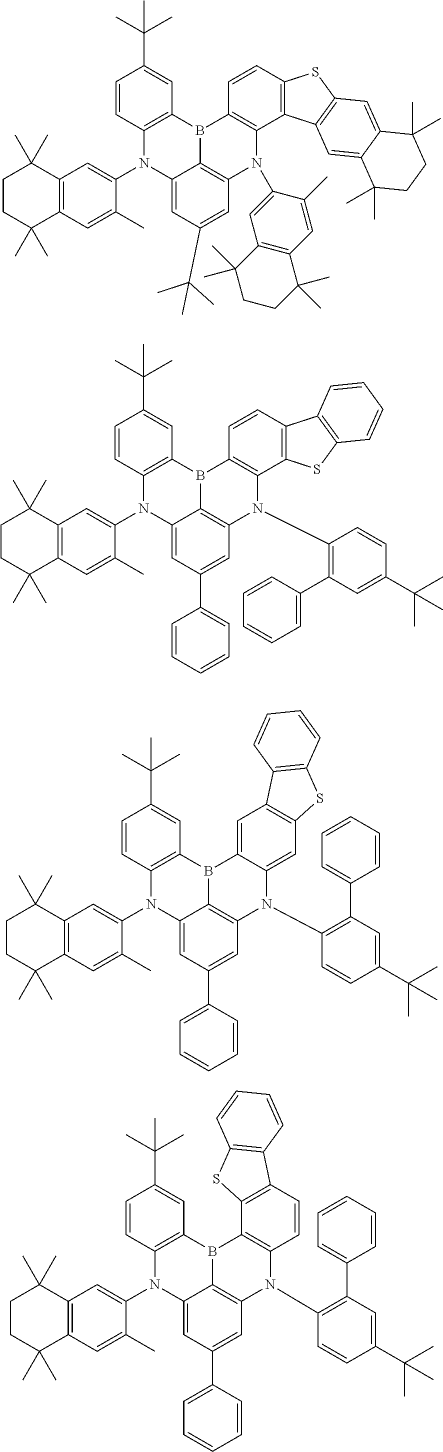

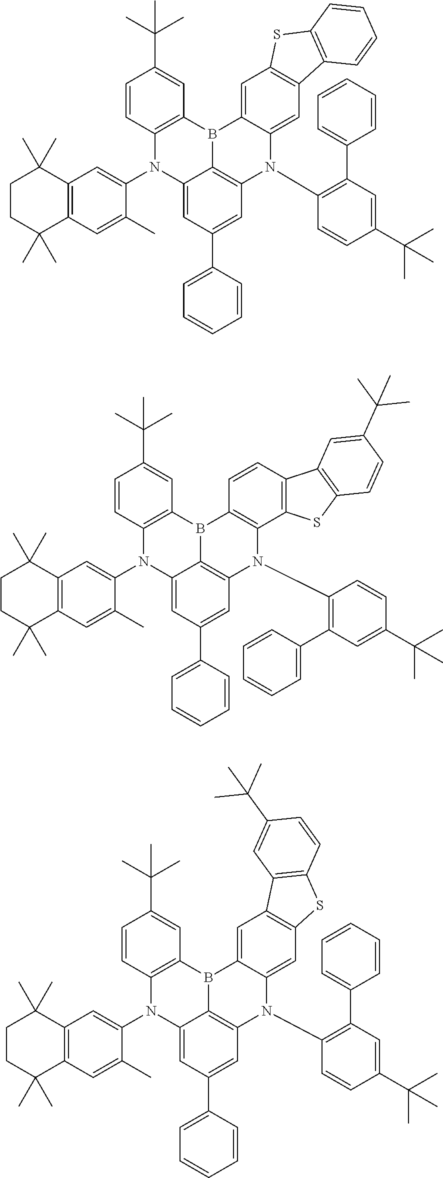 [SMILES: Cc1cc2c(cc1N1c3ccc(C(C)(C)C)cc3B3c4cc5sc6ccccc6c5cc4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6ccccc6)cc1c43)sc1ccc(C(C)(C)C)cc15)C(C)(C)CCC2(C)C]

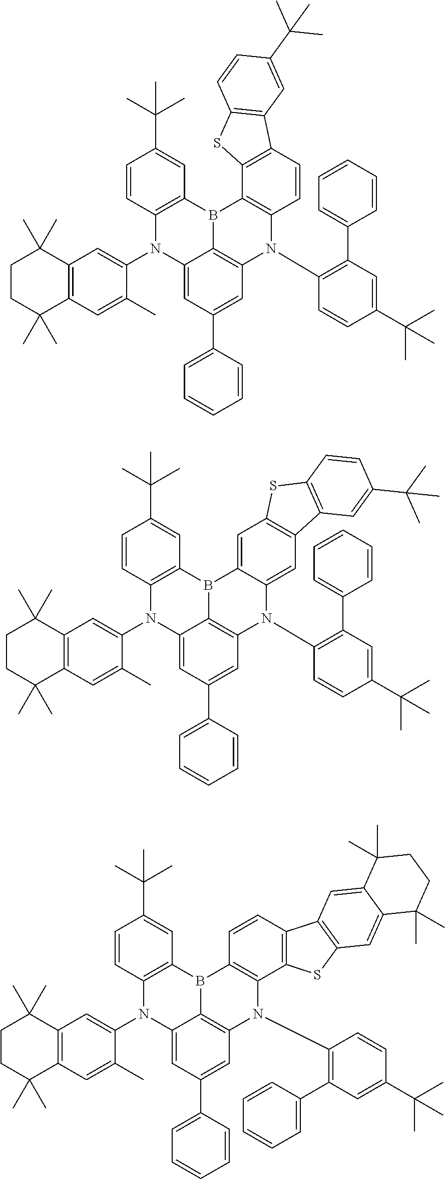 [SMILES: Cc1cc2c(cc1N1c3ccc(C(C)(C)C)cc3B3c4c1cc(-c1ccccc1)cc4N(c1ccc(C(C)(C)C)cc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4cc5sc6ccc(C(C)(C)C)cc6c5cc4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccc(C(C)(C)C)cc4-c4ccccc4)c4cc(-c5ccccc5)cc1c43)C(C)(C)CCC2(C)C]

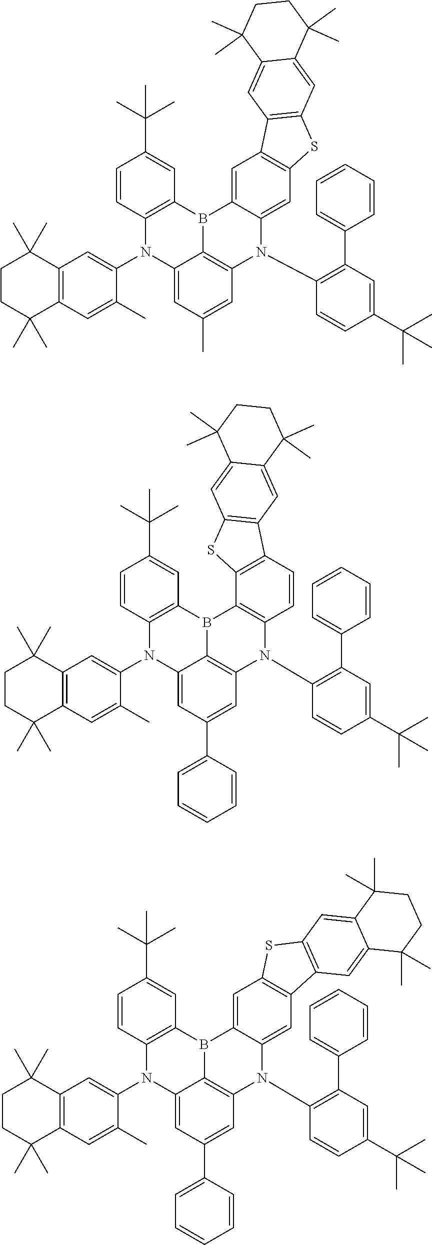 [SMILES: Cc1cc2c3c(c1)N(c1ccc(C(C)(C)C)cc1-c1ccccc1)c1cc4sc5cc6c(cc5c4cc1B3c1cc(C(C)(C)C)ccc1N2c1cc2c(cc1C)C(C)(C)CCC2(C)C)C(C)(C)CCC6(C)C ; Cc1cc2c(cc1N1c3ccc(C(C)(C)C)cc3B3c4c1cc(-c1ccccc1)cc4N(c1ccc(C(C)(C)C)cc1-c1ccccc1)c1ccc4c(sc5cc6c(cc54)C(C)(C)CCC6(C)C)c13)C(C)(C)CCC2(C)C ; Cc1cc2c(cc1N1c3ccc(C(C)(C)C)cc3B3c4cc5sc6cc7c(cc6c5cc4N(c4ccc(C(C)(C)C)cc4-c4ccccc4)c4cc(-c5ccccc5)cc1c43)C(C)(C)CCC7(C)C)C(C)(C)CCC2(C)C]

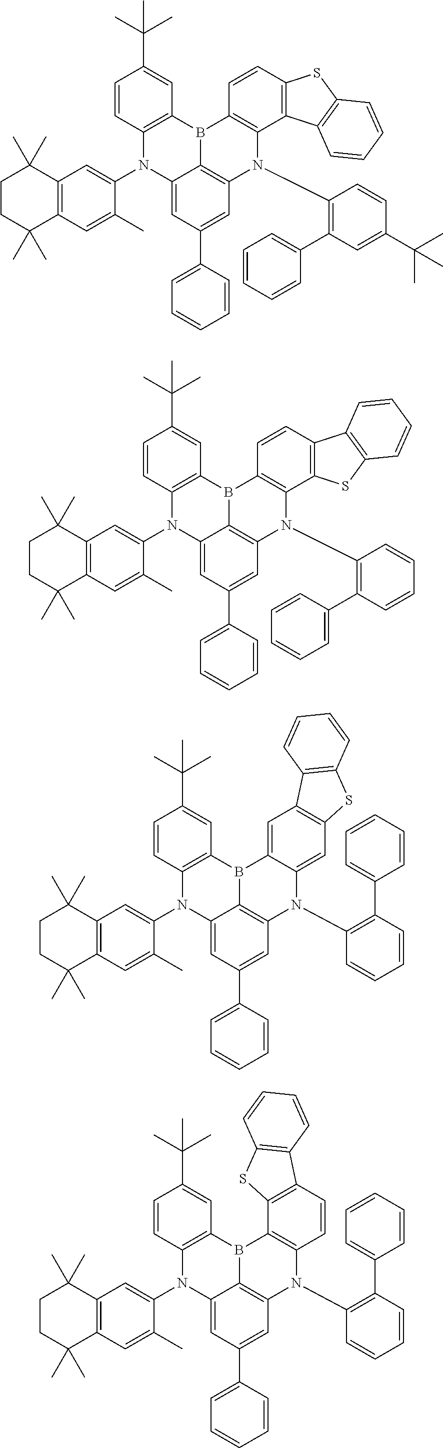

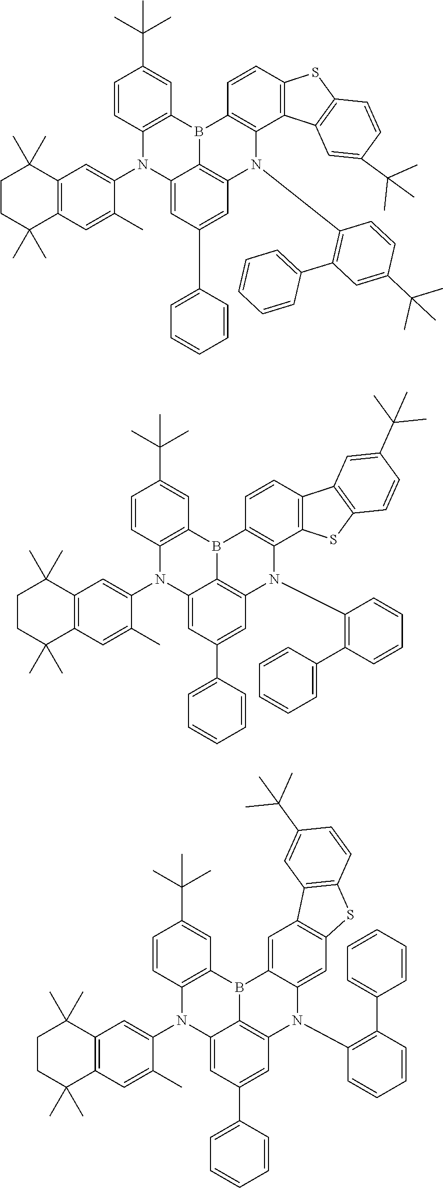 [SMILES: Cc1cc2c(cc1N1c3ccc(C(C)(C)C)cc3B3c4ccc5sc6ccc(C(C)(C)C)cc6c5c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(-c6ccccc6)cc1c43)sc1ccc(C(C)(C)C)cc15)C(C)(C)CCC2(C)C]

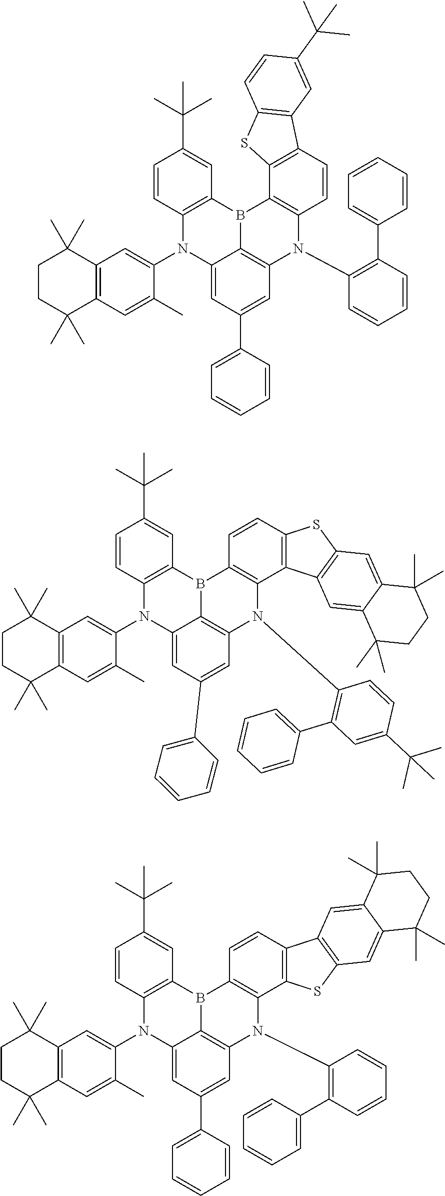 [SMILES: Cc1cc2c(cc1N1c3ccc(C(C)(C)C)cc3B3c4c1cc(-c1ccccc1)cc4N(c1ccccc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4ccc5sc6cc7c(cc6c5c4N(c4ccc(C(C)(C)C)cc4-c4ccccc4)c4cc(-c5ccccc5)cc1c43)C(C)(C)CCC7(C)C)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccccc4-c4ccccc4)c4cc(-c5ccccc5)cc1c43)C(C)(C)CCC2(C)C]

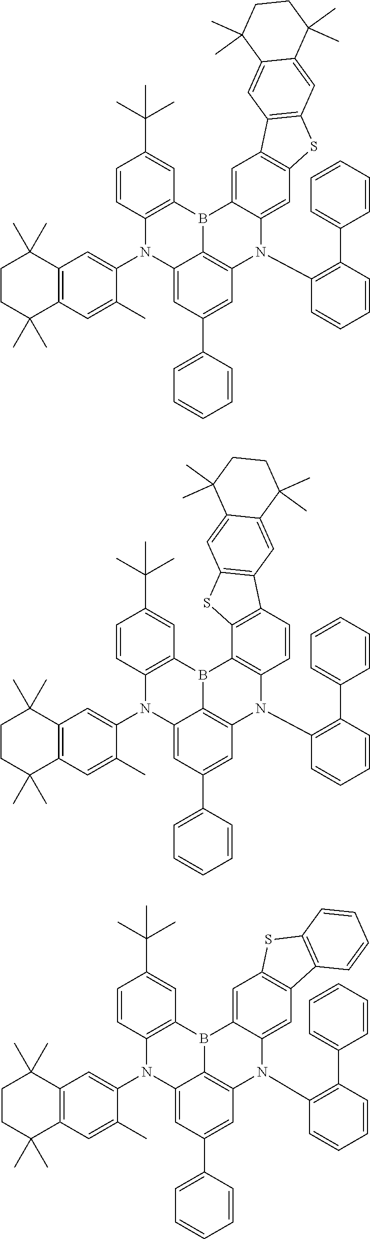 [SMILES: Cc1cc2c(cc1N1c3ccc(C(C)(C)C)cc3B3c4cc5c(cc4N(c4ccccc4-c4ccccc4)c4cc(-c6ccccc6)cc1c43)sc1cc3c(cc15)C(C)(C)CCC3(C)C)C(C)(C)CCC2(C)C ; Cc1cc2c(cc1N1c3ccc(C(C)(C)C)cc3B3c4c1cc(-c1ccccc1)cc4N(c1ccccc1-c1ccccc1)c1ccc4c(sc5cc6c(cc54)C(C)(C)CCC6(C)C)c13)C(C)(C)CCC2(C)C ; Cc1cc2c(cc1N1c3ccc(C(C)(C)C)cc3B3c4cc5sc6ccccc6c5cc4N(c4ccccc4-c4ccccc4)c4cc(-c5ccccc5)cc1c43)C(C)(C)CCC2(C)C]

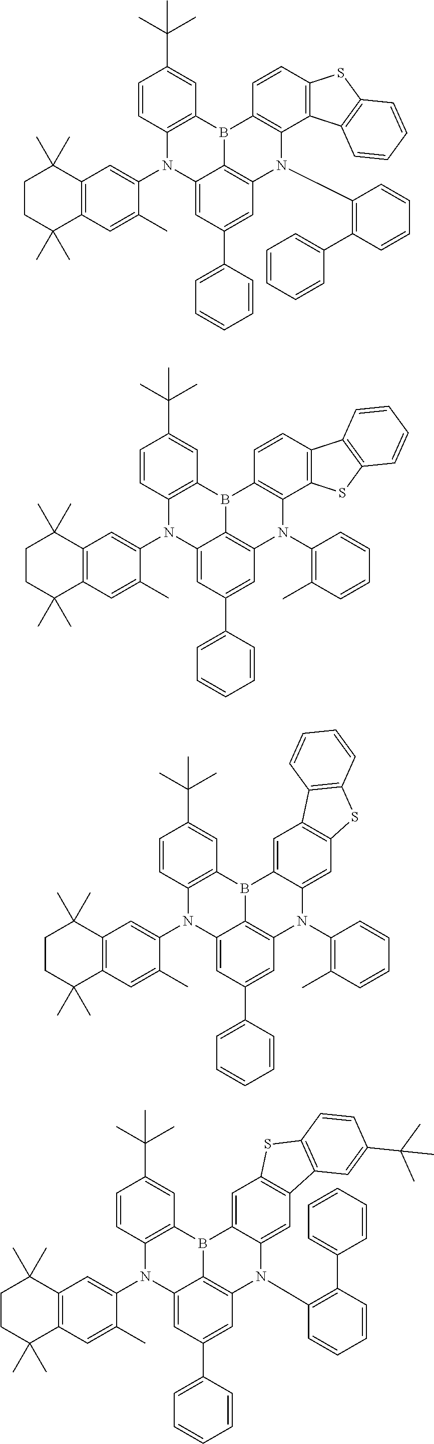 [SMILES: Cc1cc2c(cc1N1c3ccc(C(C)(C)C)cc3B3c4ccc5sc6ccccc6c5c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccccc65)c4N(c4ccccc4C)c4cc(-c5ccccc5)cc1c43)C(C)(C)CCC2(C)C ; Cc1ccccc1N1c2cc3sc4ccccc4c3cc2B2c3cc(C(C)(C)C)ccc3N(c3cc4c(cc3C)C(C)(C)CCC4(C)C)c3cc(-c4ccccc4)cc1c32 ; Cc1cc2c(cc1N1c3ccc(C(C)(C)C)cc3B3c4cc5sc6ccc(C(C)(C)C)cc6c5cc4N(c4ccccc4-c4ccccc4)c4cc(-c5ccccc5)cc1c43)C(C)(C)CCC2(C)C]

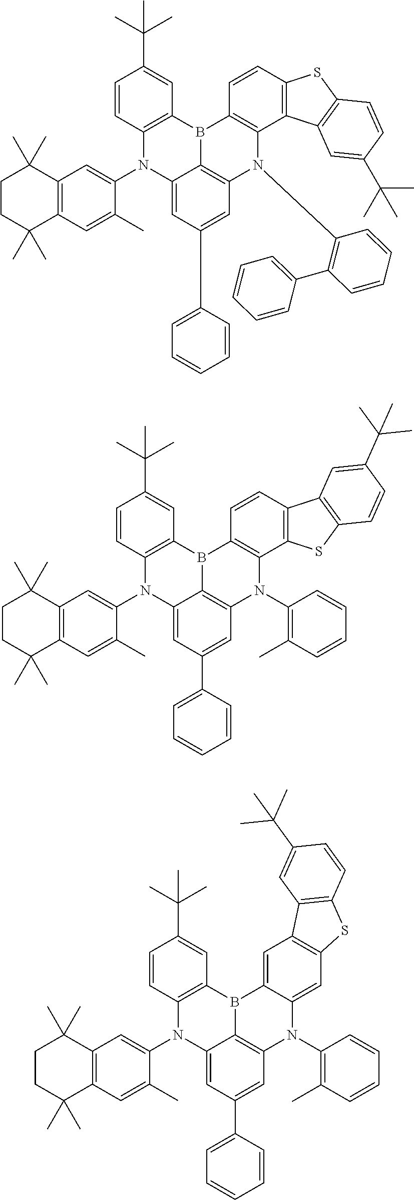 [SMILES: Cc1cc2c(cc1N1c3ccc(C(C)(C)C)cc3B3c4ccc5sc6ccc(C(C)(C)C)cc6c5c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4C)c4cc(-c5ccccc5)cc1c43)C(C)(C)CCC2(C)C ; Cc1ccccc1N1c2cc3sc4ccc(C(C)(C)C)cc4c3cc2B2c3cc(C(C)(C)C)ccc3N(c3cc4c(cc3C)C(C)(C)CCC4(C)C)c3cc(-c4ccccc4)cc1c32]

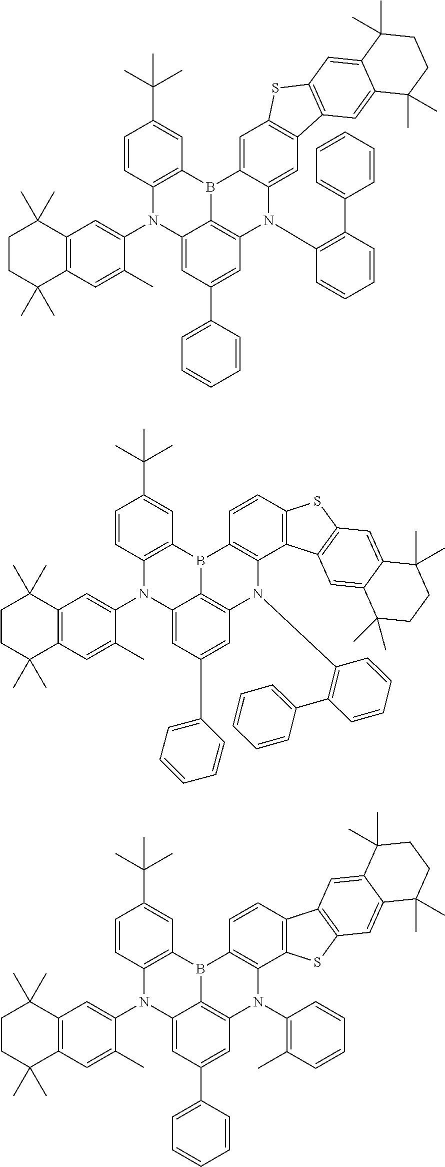 [SMILES: Cc1cc2c(cc1N1c3ccc(C(C)(C)C)cc3B3c4cc5sc6cc7c(cc6c5cc4N(c4ccccc4-c4ccccc4)c4cc(-c5ccccc5)cc1c43)C(C)(C)CCC7(C)C)C(C)(C)CCC2(C)C ; Cc1cc2c(cc1N1c3ccc(C(C)(C)C)cc3B3c4ccc5sc6cc7c(cc6c5c4N(c4ccccc4-c4ccccc4)c4cc(-c5ccccc5)cc1c43)C(C)(C)CCC7(C)C)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccccc4C)c4cc(-c5ccccc5)cc1c43)C(C)(C)CCC2(C)C]

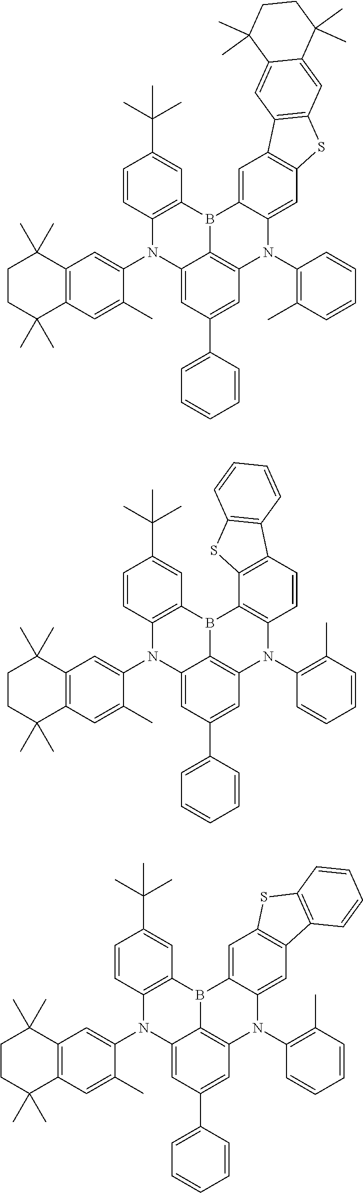 [SMILES: Cc1ccccc1N1c2cc3sc4cc5c(cc4c3cc2B2c3cc(C(C)(C)C)ccc3N(c3cc4c(cc3C)C(C)(C)CCC4(C)C)c3cc(-c4ccccc4)cc1c32)C(C)(C)CCC5(C)C ; Cc1cc2c(cc1N1c3ccc(C(C)(C)C)cc3B3c4c1cc(-c1ccccc1)cc4N(c1ccccc1C)c1ccc4c(sc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5ccccc5)cc1c42)sc1ccccc13]

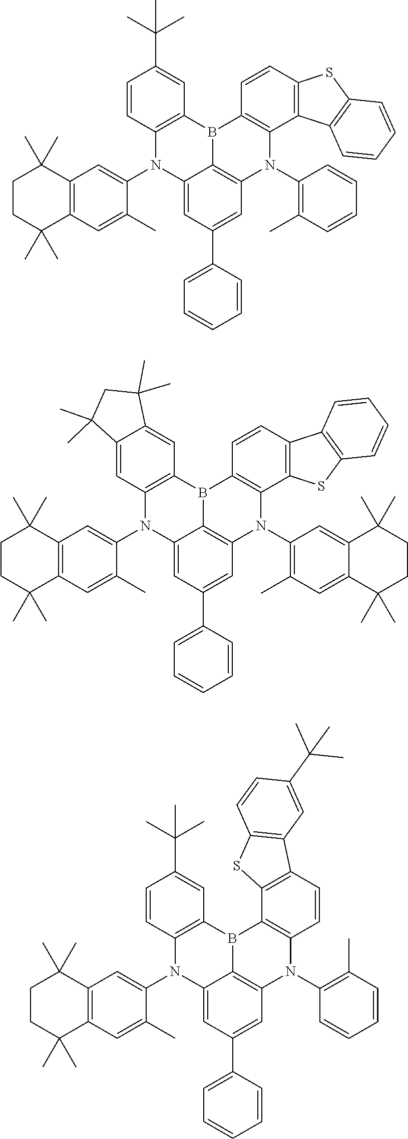 [SMILES: Cc1cc2c(cc1N1c3ccc(C(C)(C)C)cc3B3c4ccc5sc6ccccc6c5c4N(c4ccccc4C)c4cc(-c5ccccc5)cc1c43)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(-c6ccccc6)cc1c53)C(C)(C)CC4(C)C)C(C)(C)CCC2(C)C ; Cc1cc2c(cc1N1c3ccc(C(C)(C)C)cc3B3c4c1cc(-c1ccccc1)cc4N(c1ccccc1C)c1ccc4c(sc5ccc(C(C)(C)C)cc54)c13)C(C)(C)CCC2(C)C]

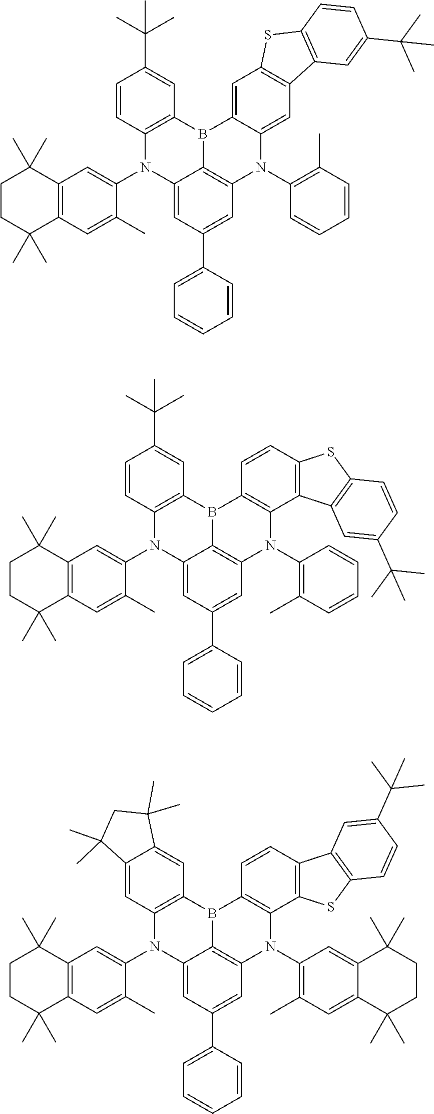 [SMILES: Cc1ccccc1N1c2cc3c(cc2B2c4cc(C(C)(C)C)ccc4N(c4cc5c(cc4C)C(C)(C)CCC5(C)C)c4cc(-c5ccccc5)cc1c42)sc1ccc(C(C)(C)C)cc13 ; Cc1cc2c(cc1N1c3ccc(C(C)(C)C)cc3B3c4ccc5sc6ccc(C(C)(C)C)cc6c5c4N(c4ccccc4C)c4cc(-c5ccccc5)cc1c43)C(C)(C)CCC2(C)C ; Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6ccccc6)cc1c53)C(C)(C)CC4(C)C)C(C)(C)CCC2(C)C]

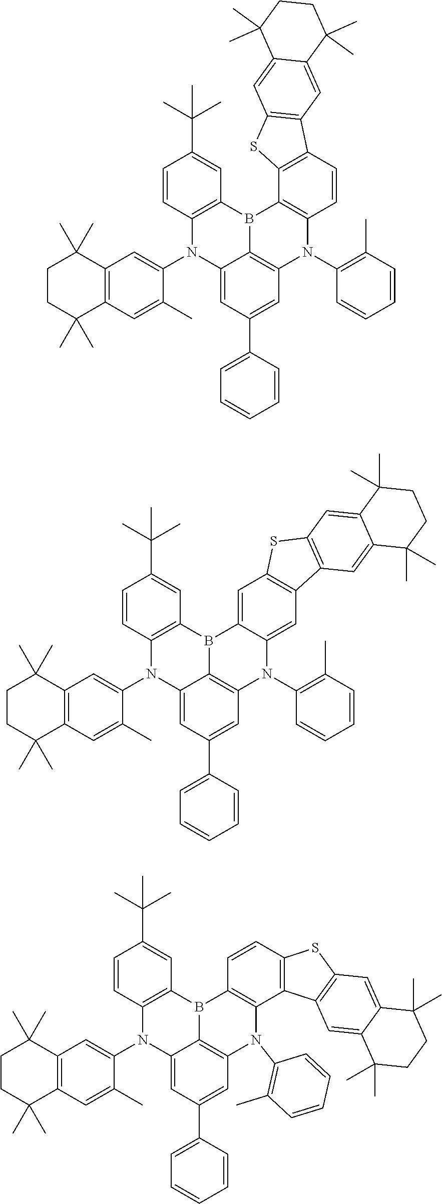 [SMILES: Cc1cc2c(cc1N1c3ccc(C(C)(C)C)cc3B3c4c1cc(-c1ccccc1)cc4N(c1ccccc1C)c1ccc4c(sc5cc6c(cc54)C(C)(C)CCC6(C)C)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5ccccc5)cc1c42)sc1cc2c(cc13)C(C)(C)CCC2(C)C ; Cc1cc2c(cc1N1c3ccc(C(C)(C)C)cc3B3c4ccc5sc6cc7c(cc6c5c4N(c4ccccc4C)c4cc(-c5ccccc5)cc1c43)C(C)(C)CCC7(C)C)C(C)(C)CCC2(C)C]

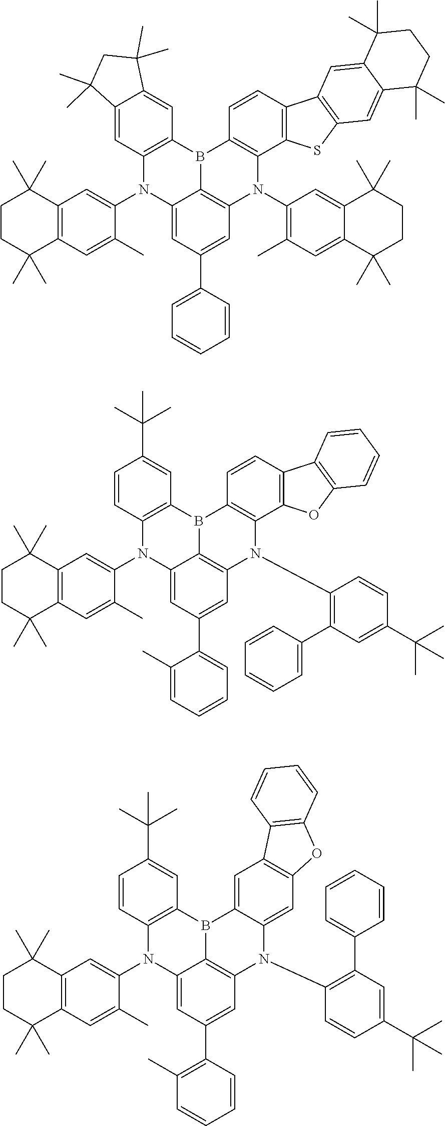 [SMILES: Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(-c6ccccc6)cc1c53)C(C)(C)CC4(C)C)C(C)(C)CCC2(C)C ; Cc1ccccc1-c1cc2c3c(c1)N(c1ccc(C(C)(C)C)cc1-c1ccccc1)c1c(ccc4c1oc1ccccc14)B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4oc5ccccc5c4cc1B3c1cc(C(C)(C)C)ccc1N2c1cc2c(cc1C)C(C)(C)CCC2(C)C]

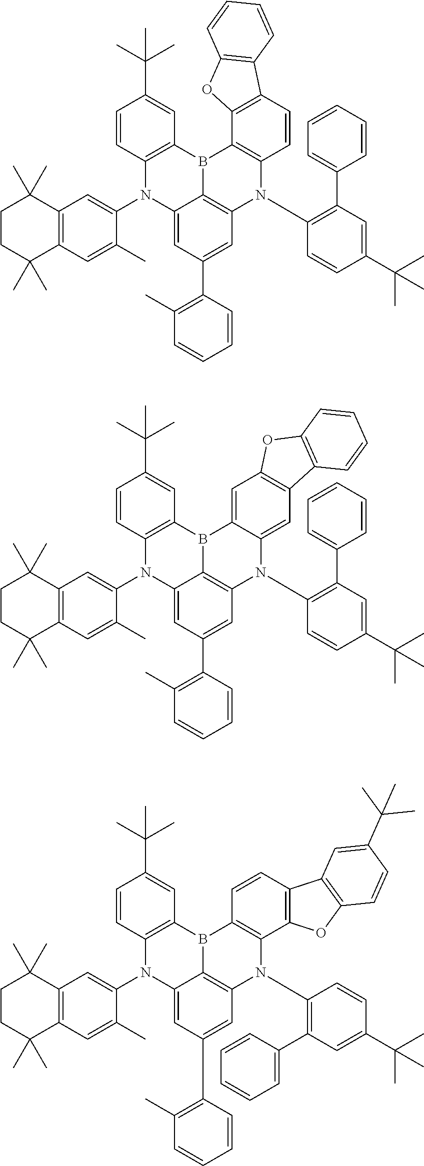 [SMILES: Cc1ccccc1-c1cc2c3c(c1)N(c1ccc(C(C)(C)C)cc1-c1ccccc1)c1ccc4c(oc5ccccc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)oc1ccccc14 ; Cc1ccccc1-c1cc2c3c(c1)N(c1ccc(C(C)(C)C)cc1-c1ccccc1)c1c(ccc4c1oc1ccc(C(C)(C)C)cc14)B3c1cc(C(C)(C)C)ccc1N2c1cc2c(cc1C)C(C)(C)CCC2(C)C]

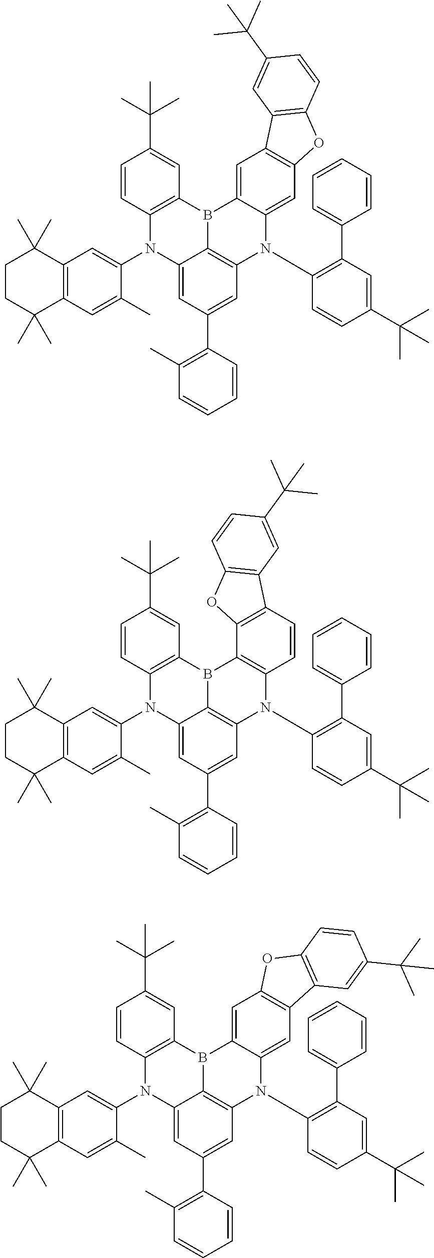 [SMILES: Cc1ccccc1-c1cc2c3c(c1)N(c1ccc(C(C)(C)C)cc1-c1ccccc1)c1cc4oc5ccc(C(C)(C)C)cc5c4cc1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1ccc4c(oc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)oc1ccc(C(C)(C)C)cc14]

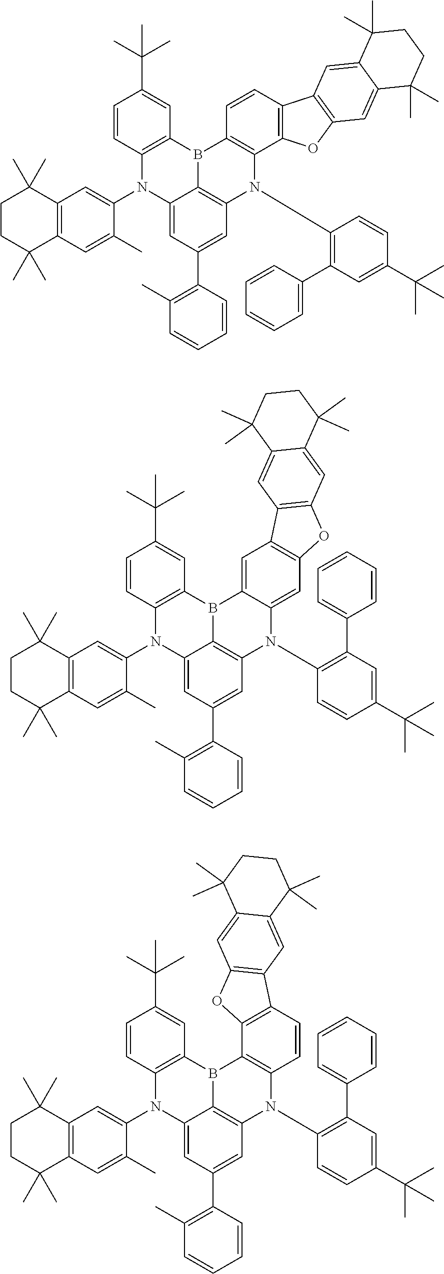 [SMILES: Cc1ccccc1-c1cc2c3c(c1)N(c1ccc(C(C)(C)C)cc1-c1ccccc1)c1c(ccc4c1oc1cc5c(cc14)C(C)(C)CCC5(C)C)B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4oc5cc6c(cc5c4cc1B3c1cc(C(C)(C)C)ccc1N2c1cc2c(cc1C)C(C)(C)CCC2(C)C)C(C)(C)CCC6(C)C ; Cc1ccccc1-c1cc2c3c(c1)N(c1ccc(C(C)(C)C)cc1-c1ccccc1)c1ccc4c(oc5cc6c(cc54)C(C)(C)CCC6(C)C)c1B3c1cc(C(C)(C)C)ccc1N2c1cc2c(cc1C)C(C)(C)CCC2(C)C]

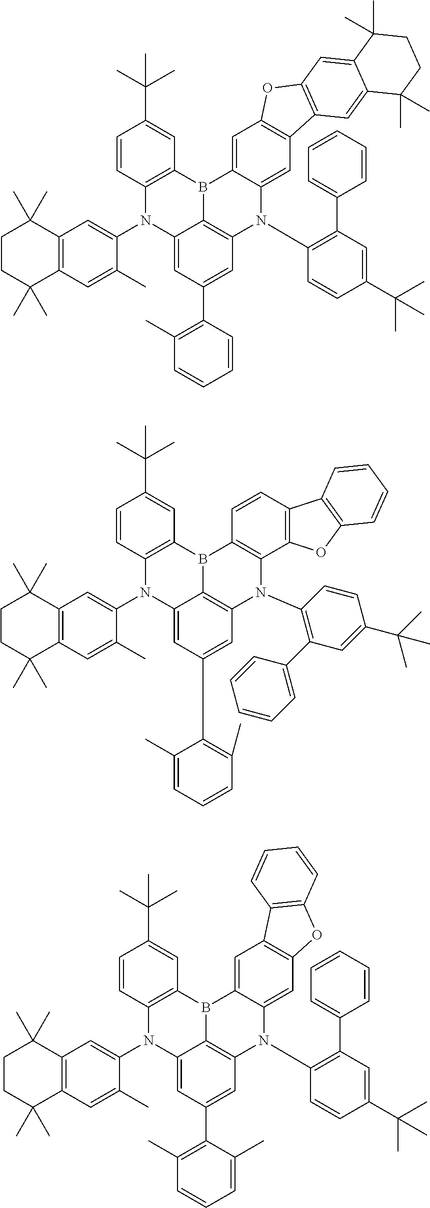 [SMILES: Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1cc2c(cc1N1c3ccc(C(C)(C)C)cc3B3c4ccc5c(oc6ccccc65)c4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6c(C)cccc6C)cc1c43)oc1ccccc15)C(C)(C)CCC2(C)C]

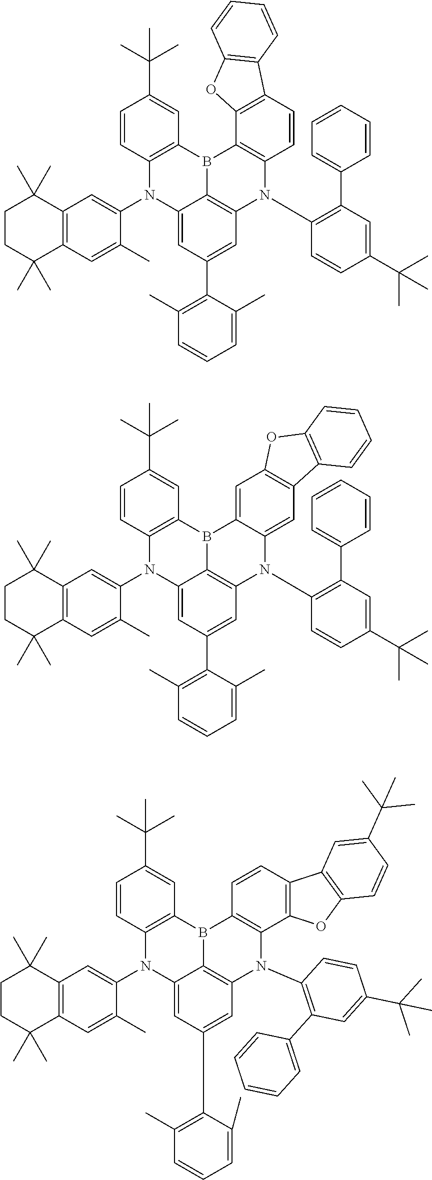 [SMILES: Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(oc5ccccc54)c13)C(C)(C)CCC2(C)C ; Cc1cc2c(cc1N1c3ccc(C(C)(C)C)cc3B3c4cc5oc6ccccc6c5cc4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4ccc(C(C)(C)C)cc4-c4ccccc4)c4cc(-c5c(C)cccc5C)cc1c43)C(C)(C)CCC2(C)C]

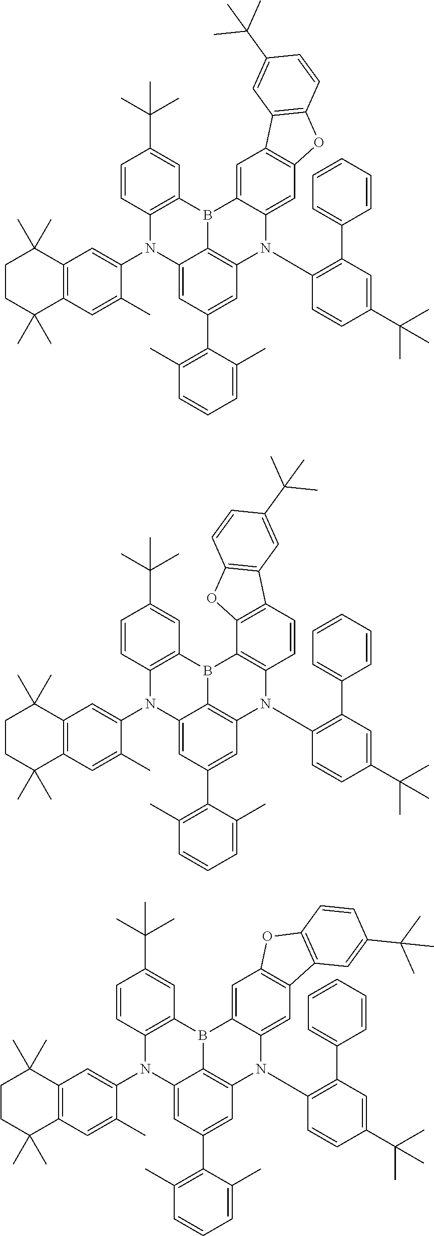 [SMILES: Cc1cc2c(cc1N1c3ccc(C(C)(C)C)cc3B3c4cc5c(cc4N(c4ccc(C(C)(C)C)cc4-c4ccccc4)c4cc(-c6c(C)cccc6C)cc1c43)oc1ccc(C(C)(C)C)cc15)C(C)(C)CCC2(C)C ; Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(oc5ccc(C(C)(C)C)cc54)c13)C(C)(C)CCC2(C)C ; Cc1cc2c(cc1N1c3ccc(C(C)(C)C)cc3B3c4cc5oc6ccc(C(C)(C)C)cc6c5cc4N(c4ccc(C(C)(C)C)cc4-c4ccccc4)c4cc(-c5c(C)cccc5C)cc1c43)C(C)(C)CCC2(C)C]

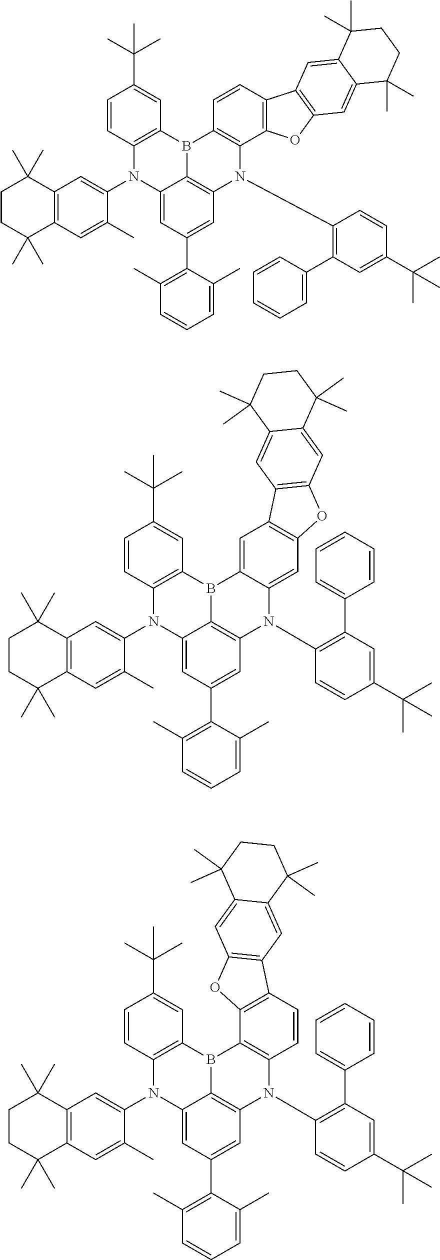 [SMILES: Cc1cc2c(cc1N1c3ccc(C(C)(C)C)cc3B3c4ccc5c(oc6cc7c(cc65)C(C)(C)CCC7(C)C)c4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6c(C)cccc6C)cc1c43)oc1cc3c(cc15)C(C)(C)CCC3(C)C)C(C)(C)CCC2(C)C ; Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(oc5cc6c(cc54)C(C)(C)CCC6(C)C)c13)C(C)(C)CCC2(C)C]

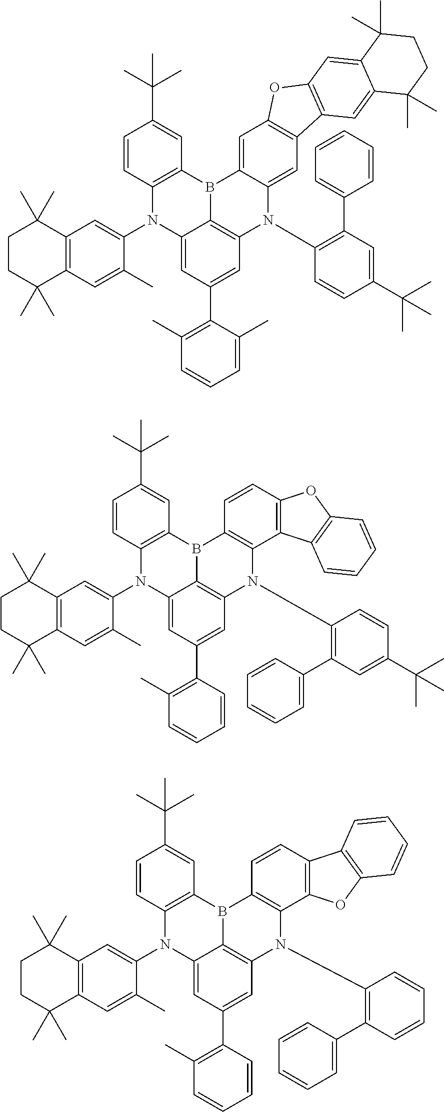 [SMILES: Cc1cc2c(cc1N1c3ccc(C(C)(C)C)cc3B3c4cc5oc6cc7c(cc6c5cc4N(c4ccc(C(C)(C)C)cc4-c4ccccc4)c4cc(-c5c(C)cccc5C)cc1c43)C(C)(C)CCC7(C)C)C(C)(C)CCC2(C)C ; Cc1ccccc1-c1cc2c3c(c1)N(c1ccc(C(C)(C)C)cc1-c1ccccc1)c1c(ccc4oc5ccccc5c14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1oc1ccccc14)B3c1cc(C(C)(C)C)ccc1N2c1cc2c(cc1C)C(C)(C)CCC2(C)C]

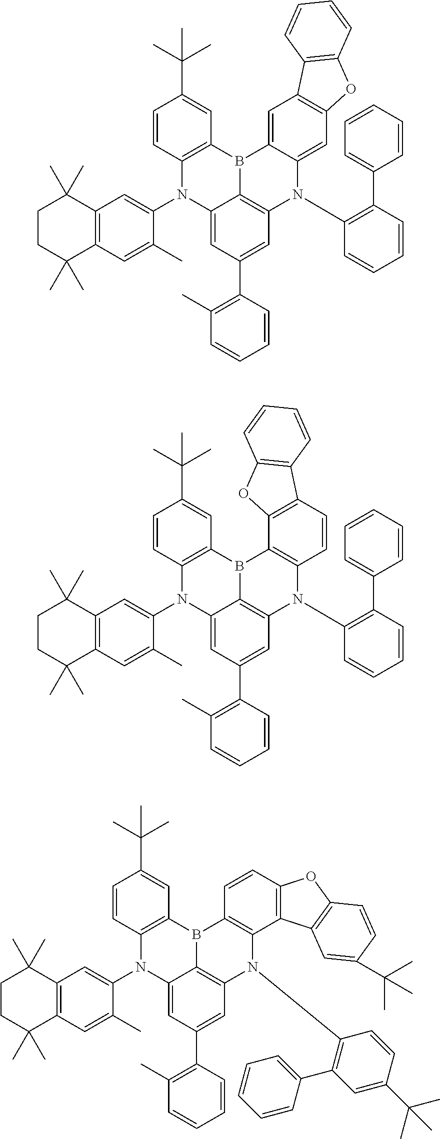 [SMILES: Cc1ccccc1-c1cc2c3c(c1)N(c1ccccc1-c1ccccc1)c1cc4oc5ccccc5c4cc1B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1ccc4c(oc5ccccc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1c(ccc4oc5ccc(C(C)(C)C)cc5c14)B3c1cc(C(C)(C)C)ccc1N2c1cc2c(cc1C)C(C)(C)CCC2(C)C]

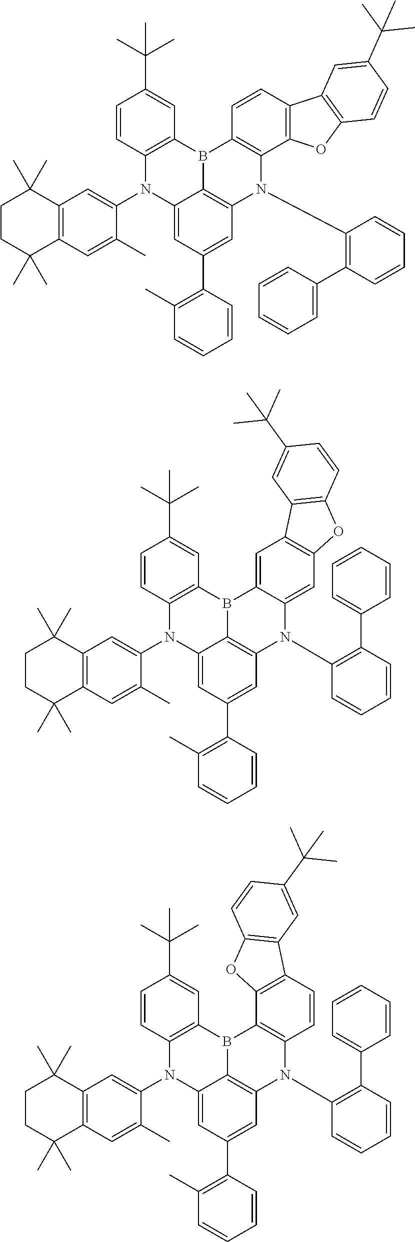 [SMILES: Cc1ccccc1-c1cc2c3c(c1)N(c1ccccc1-c1ccccc1)c1c(ccc4c1oc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4oc5ccc(C(C)(C)C)cc5c4cc1B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1ccc4c(oc5ccc(C(C)(C)C)cc54)c1B3c1cc(C(C)(C)C)ccc1N2c1cc2c(cc1C)C(C)(C)CCC2(C)C]

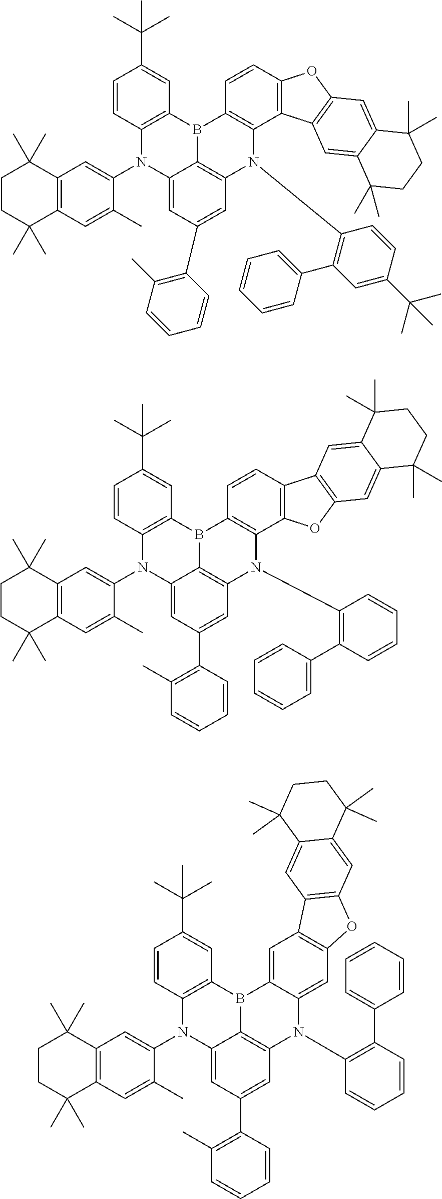 [SMILES: Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1oc1cc5c(cc14)C(C)(C)CCC5(C)C)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4oc5cc6c(cc5c4cc1B3c1cc(C(C)(C)C)ccc1N2c1cc2c(cc1C)C(C)(C)CCC2(C)C)C(C)(C)CCC6(C)C]

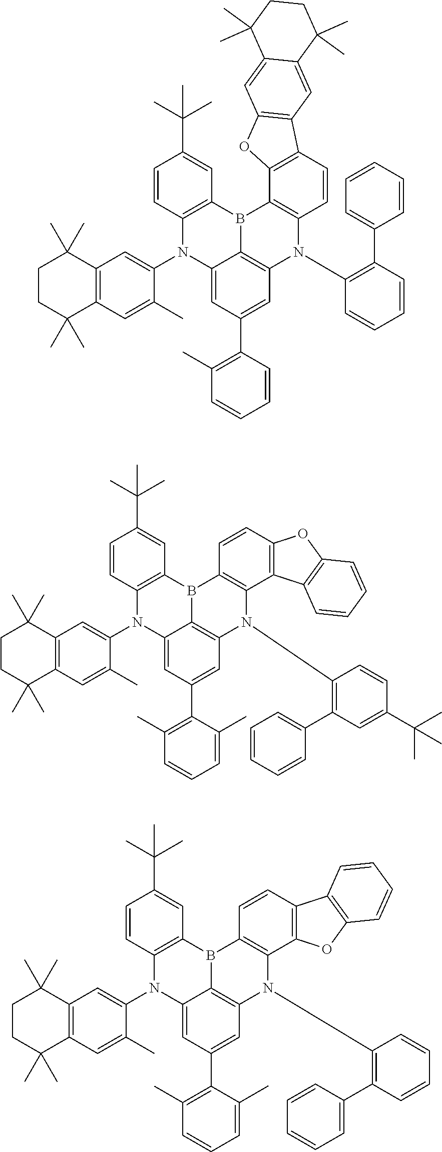 [SMILES: Cc1ccccc1-c1cc2c3c(c1)N(c1ccccc1-c1ccccc1)c1ccc4c(oc5cc6c(cc54)C(C)(C)CCC6(C)C)c1B3c1cc(C(C)(C)C)ccc1N2c1cc2c(cc1C)C(C)(C)CCC2(C)C ; Cc1cc2c(cc1N1c3ccc(C(C)(C)C)cc3B3c4ccc5oc6ccccc6c5c4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccccc65)c4N(c4ccccc4-c4ccccc4)c4cc(-c5c(C)cccc5C)cc1c43)C(C)(C)CCC2(C)C]

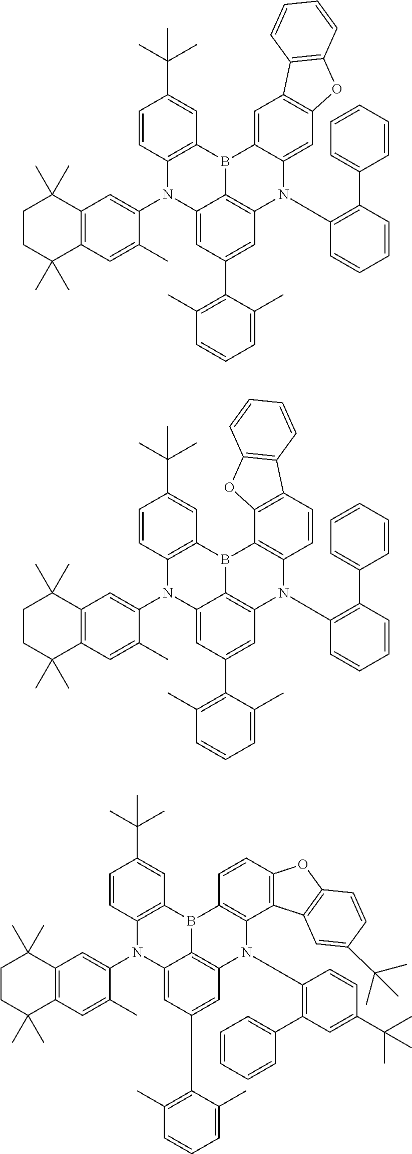

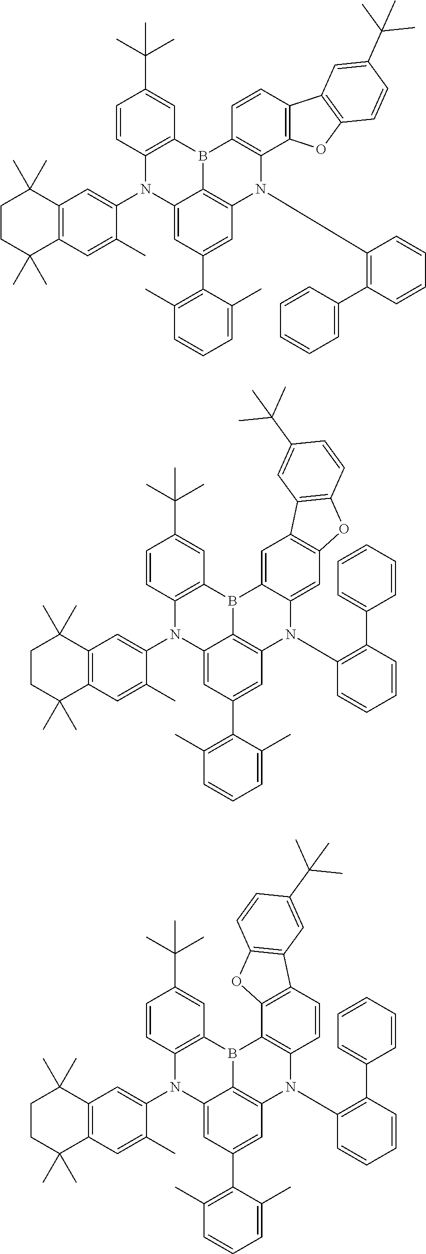

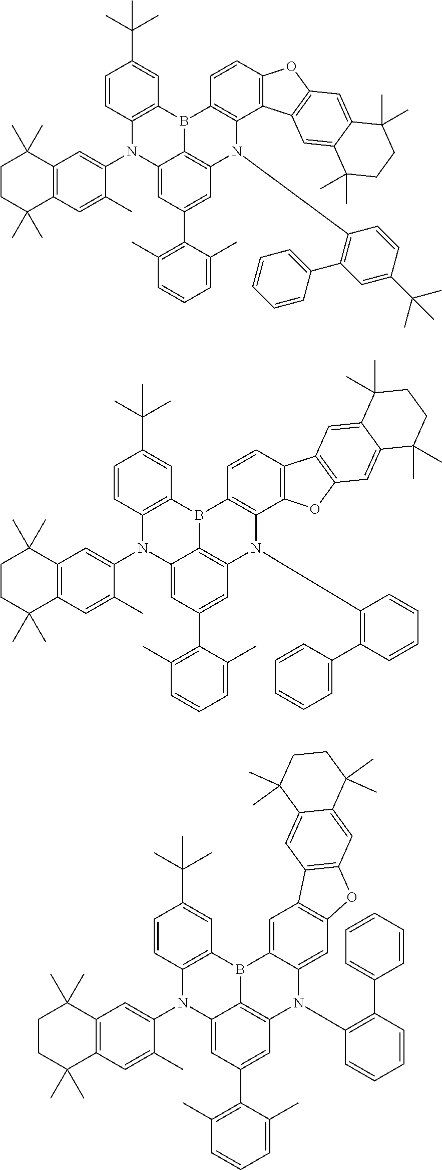

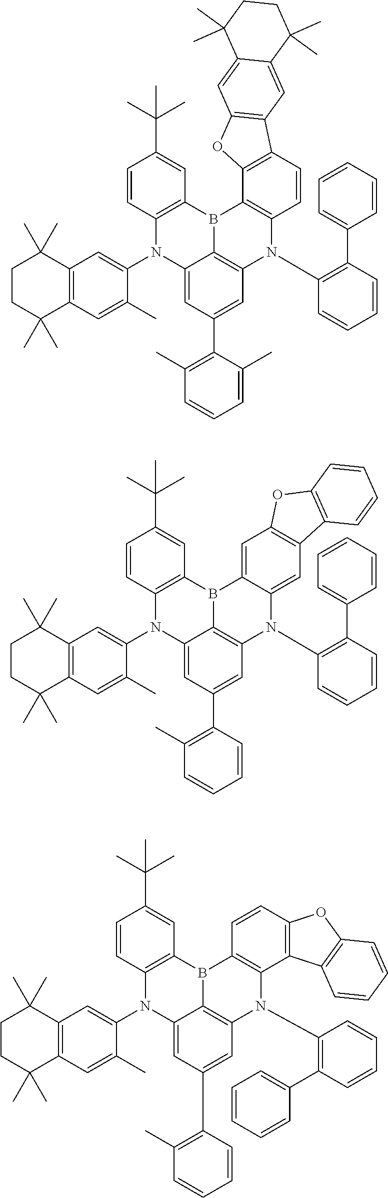 [SMILES: Cc1cc2c(cc1N1c3ccc(C(C)(C)C)cc3B3c4c1cc(-c1c(C)cccc1C)cc4N(c1ccccc1-c1ccccc1)c1ccc4c(oc5cc6c(cc54)C(C)(C)CCC6(C)C)c13)C(C)(C)CCC2(C)C ; Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1ccccc14 ; Cc1ccccc1-c1cc2c3c(c1)N(c1ccccc1-c1ccccc1)c1c(ccc4oc5ccccc5c14)B3c1cc(C(C)(C)C)ccc1N2c1cc2c(cc1C)C(C)(C)CCC2(C)C]

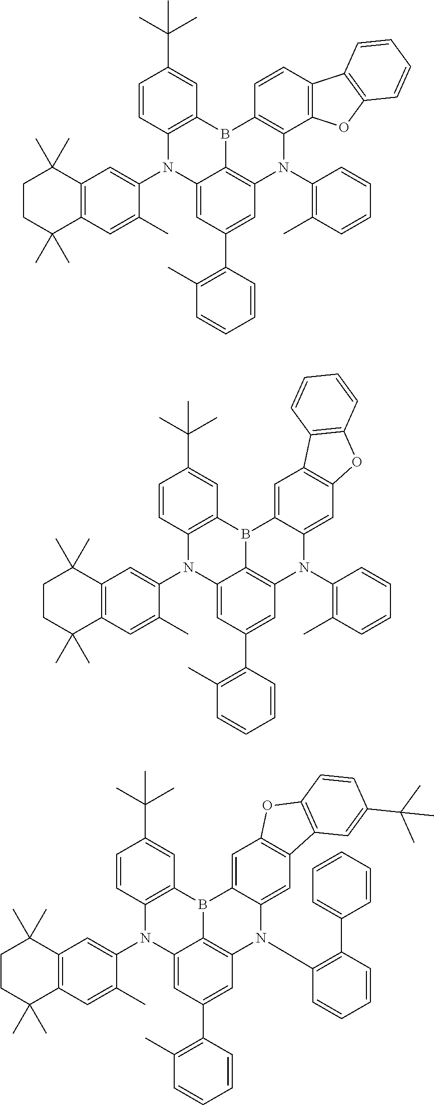 [SMILES: Cc1ccccc1-c1cc2c3c(c1)N(c1ccccc1C)c1c(ccc4c1oc1ccccc14)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4oc5ccccc5c4cc1B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1ccc(C(C)(C)C)cc14]

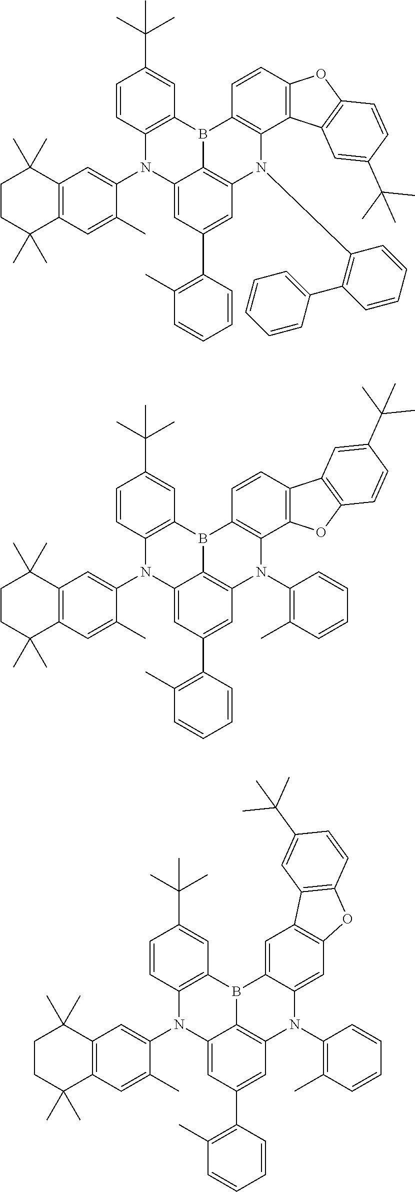 [SMILES: Cc1ccccc1-c1cc2c3c(c1)N(c1ccccc1-c1ccccc1)c1c(ccc4oc5ccc(C(C)(C)C)cc5c14)B3c1cc(C(C)(C)C)ccc1N2c1cc2c(cc1C)C(C)(C)CCC2(C)C ; Cc1ccccc1-c1cc2c3c(c1)N(c1ccccc1C)c1c(ccc4c1oc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4oc5ccc(C(C)(C)C)cc5c4cc1B3c1cc(C(C)(C)C)ccc1N2c1cc2c(cc1C)C(C)(C)CCC2(C)C]

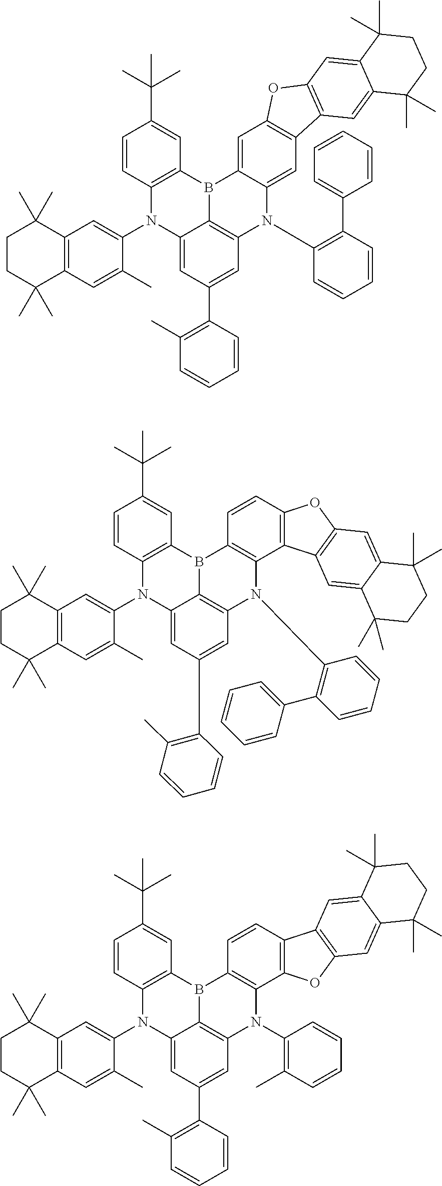 [SMILES: Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1ccccc1-c1cc2c3c(c1)N(c1ccccc1-c1ccccc1)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1ccccc1-c1cc2c3c(c1)N(c1ccccc1C)c1c(ccc4c1oc1cc5c(cc14)C(C)(C)CCC5(C)C)B3c1cc(C(C)(C)C)ccc1N2c1cc2c(cc1C)C(C)(C)CCC2(C)C]

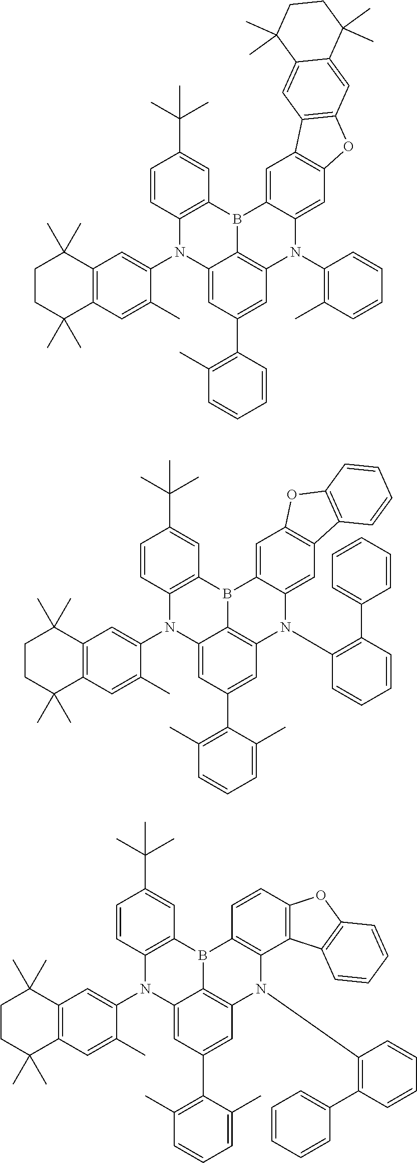 [SMILES: Cc1ccccc1-c1cc2c3c(c1)N(c1ccccc1C)c1cc4oc5cc6c(cc5c4cc1B3c1cc(C(C)(C)C)ccc1N2c1cc2c(cc1C)C(C)(C)CCC2(C)C)C(C)(C)CCC6(C)C ; Cc1cc2c(cc1N1c3ccc(C(C)(C)C)cc3B3c4cc5oc6ccccc6c5cc4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5oc6ccccc6c5c4N(c4ccccc4-c4ccccc4)c4cc(-c5c(C)cccc5C)cc1c43)C(C)(C)CCC2(C)C]

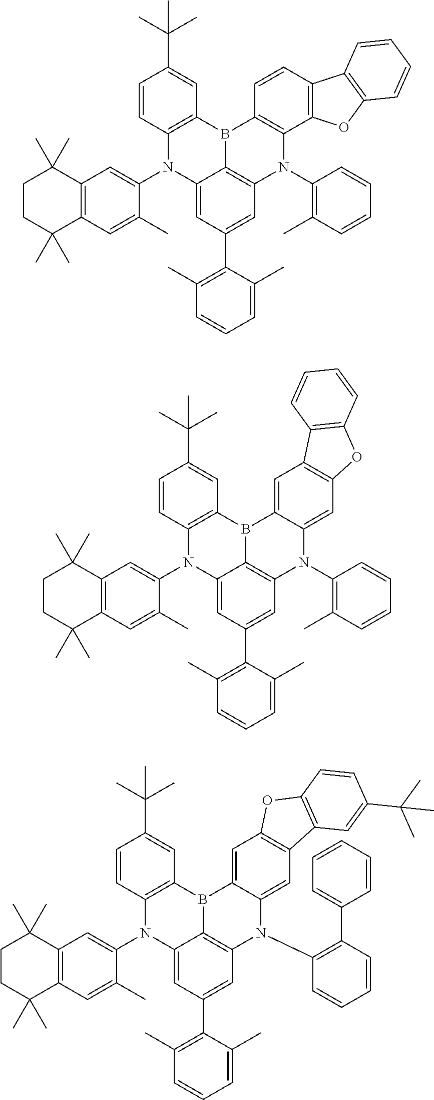 [SMILES: Cc1cc2c(cc1N1c3ccc(C(C)(C)C)cc3B3c4ccc5c(oc6ccccc65)c4N(c4ccccc4C)c4cc(-c5c(C)cccc5C)cc1c43)C(C)(C)CCC2(C)C ; Cc1ccccc1N1c2cc3oc4ccccc4c3cc2B2c3cc(C(C)(C)C)ccc3N(c3cc4c(cc3C)C(C)(C)CCC4(C)C)c3cc(-c4c(C)cccc4C)cc1c32 ; Cc1cc2c(cc1N1c3ccc(C(C)(C)C)cc3B3c4cc5oc6ccc(C(C)(C)C)cc6c5cc4N(c4ccccc4-c4ccccc4)c4cc(-c5c(C)cccc5C)cc1c43)C(C)(C)CCC2(C)C]

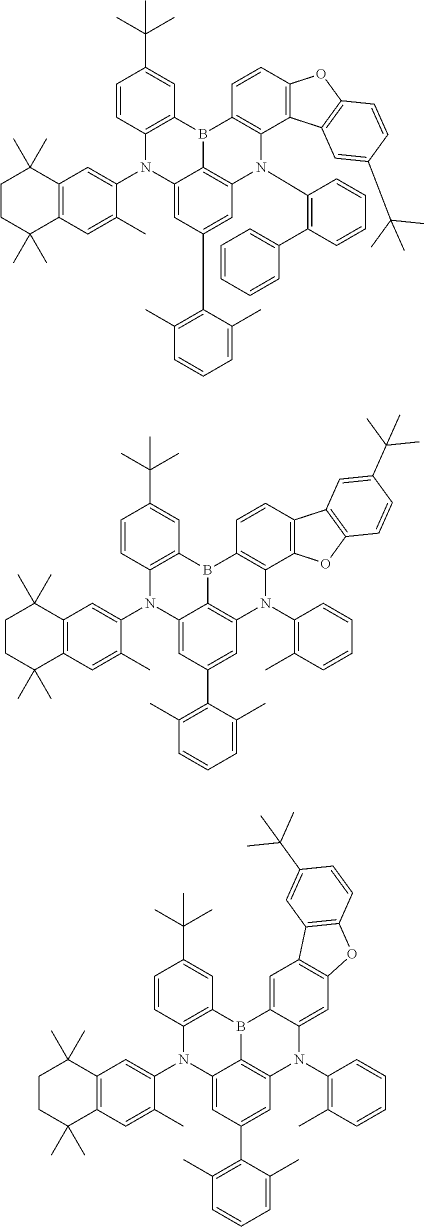 [SMILES: Cc1cc2c(cc1N1c3ccc(C(C)(C)C)cc3B3c4ccc5oc6ccc(C(C)(C)C)cc6c5c4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4ccccc4C)c4cc(-c5c(C)cccc5C)cc1c43)C(C)(C)CCC2(C)C ; Cc1ccccc1N1c2cc3oc4ccc(C(C)(C)C)cc4c3cc2B2c3cc(C(C)(C)C)ccc3N(c3cc4c(cc3C)C(C)(C)CCC4(C)C)c3cc(-c4c(C)cccc4C)cc1c32]

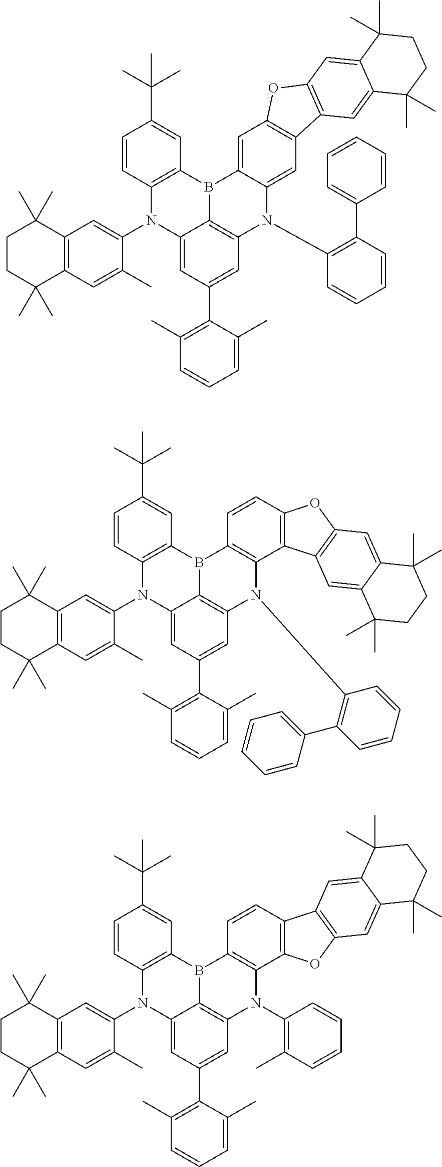 [SMILES: Cc1cc2c(cc1N1c3ccc(C(C)(C)C)cc3B3c4cc5oc6cc7c(cc6c5cc4N(c4ccccc4-c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5oc6cc7c(cc6c5c4N(c4ccccc4-c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5c(oc6cc7c(cc65)C(C)(C)CCC7(C)C)c4N(c4ccccc4C)c4cc(-c5c(C)cccc5C)cc1c43)C(C)(C)CCC2(C)C]

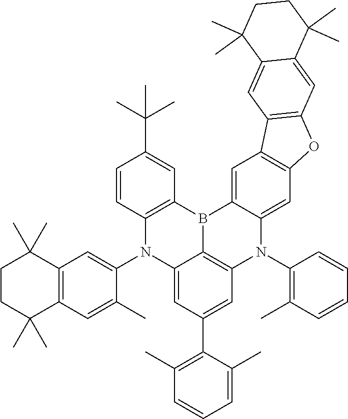 [SMILES: Cc1ccccc1N1c2cc3oc4cc5c(cc4c3cc2B2c3cc(C(C)(C)C)ccc3N(c3cc4c(cc3C)C(C)(C)CCC4(C)C)c3cc(-c4c(C)cccc4C)cc1c32)C(C)(C)CCC5(C)C]

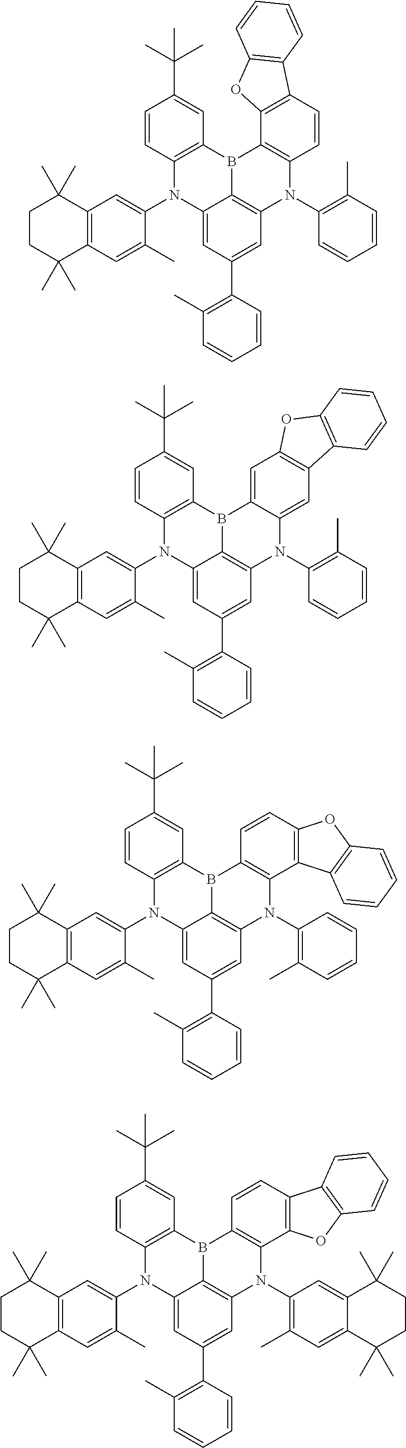 [SMILES: Cc1ccccc1-c1cc2c3c(c1)N(c1ccccc1C)c1ccc4c(oc5ccccc54)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)oc1ccccc14 ; Cc1ccccc1-c1cc2c3c(c1)N(c1ccccc1C)c1c(ccc4oc5ccccc5c14)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1oc1ccccc14)B3c1cc(C(C)(C)C)ccc1N2c1cc2c(cc1C)C(C)(C)CCC2(C)C]

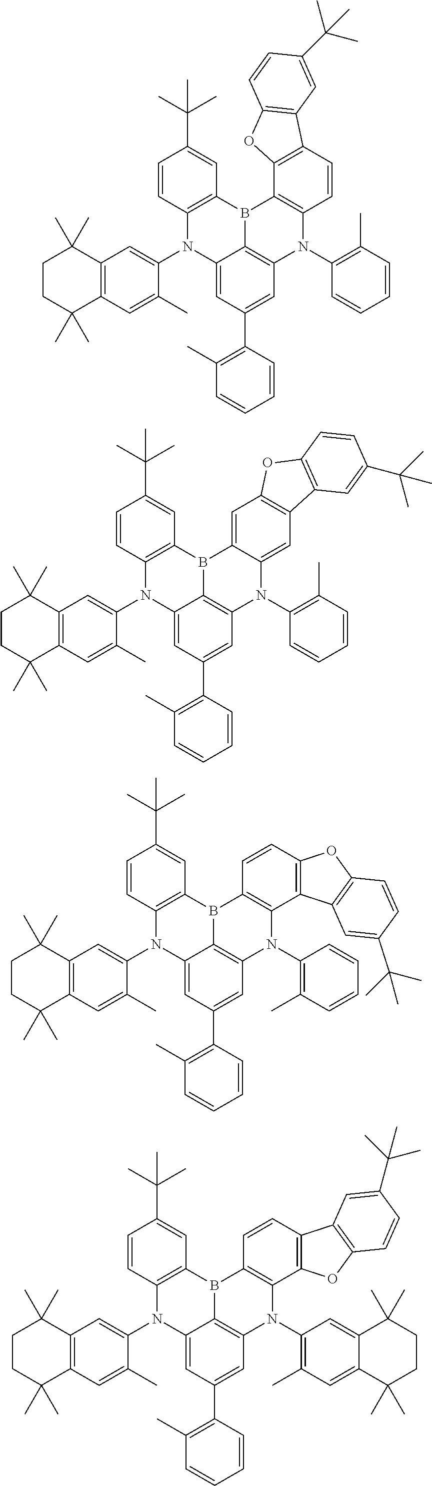

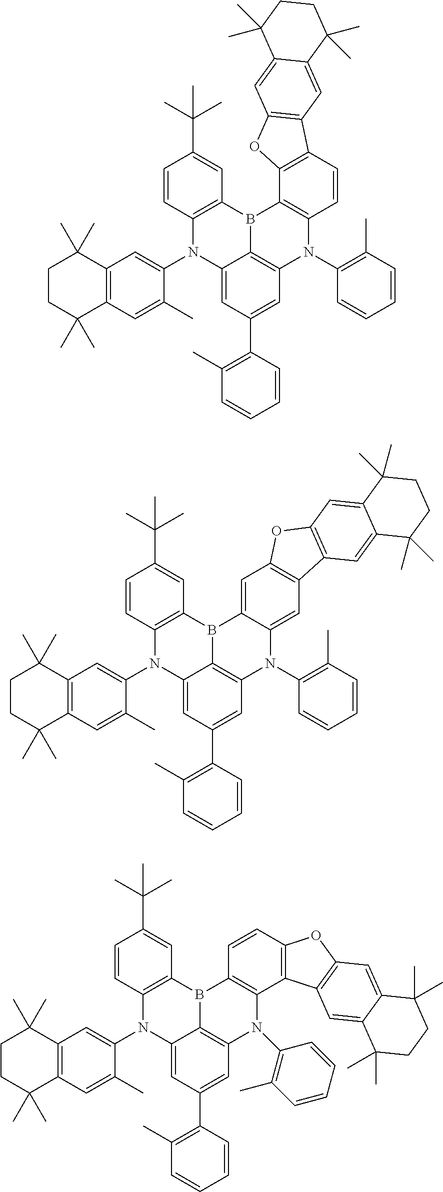 [SMILES: Cc1ccccc1-c1cc2c3c(c1)N(c1ccccc1C)c1ccc4c(oc5cc6c(cc54)C(C)(C)CCC6(C)C)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1ccccc1-c1cc2c3c(c1)N(c1ccccc1C)c1c(ccc4oc5cc6c(cc5c14)C(C)(C)CCC6(C)C)B3c1cc(C(C)(C)C)ccc1N2c1cc2c(cc1C)C(C)(C)CCC2(C)C]

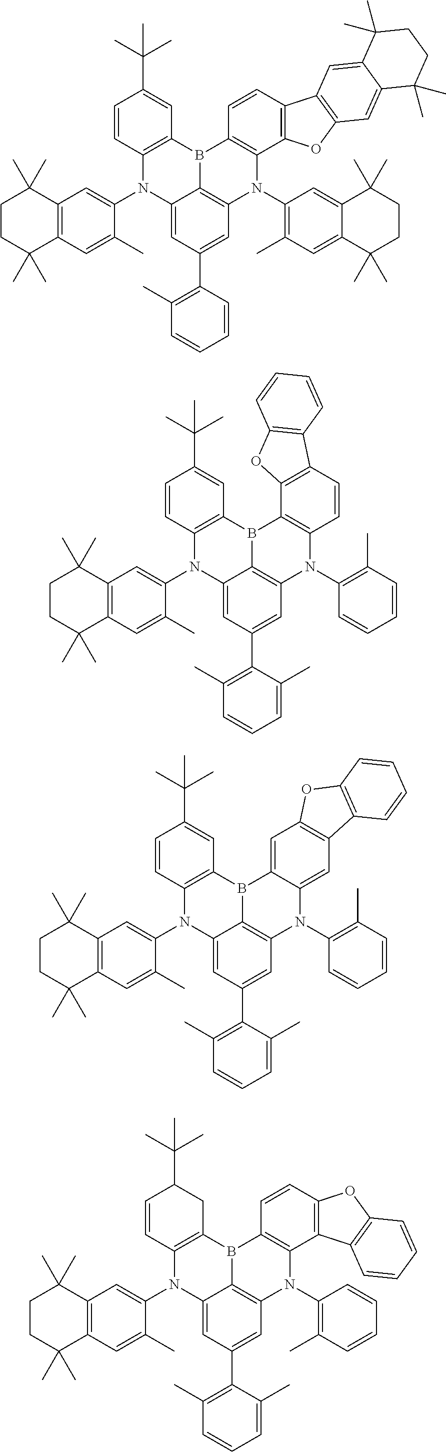 [SMILES: Cc1ccccc1-c1cc2c3c(c1)N(c1cc4c(cc1C)C(C)(C)CCC4(C)C)c1c(ccc4c1oc1cc5c(cc14)C(C)(C)CCC5(C)C)B3c1cc(C(C)(C)C)ccc1N2c1cc2c(cc1C)C(C)(C)CCC2(C)C ; Cc1cc2c(cc1N1c3ccc(C(C)(C)C)cc3B3c4c1cc(-c1c(C)cccc1C)cc4N(c1ccccc1C)c1ccc4c(oc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)oc1ccccc13 ; Cc1cc2c(cc1N1C3=C(CC(C(C)(C)C)C=C3)B3c4ccc5oc6ccccc6c5c4N(c4ccccc4C)c4cc(-c5c(C)cccc5C)cc1c43)C(C)(C)CCC2(C)C]

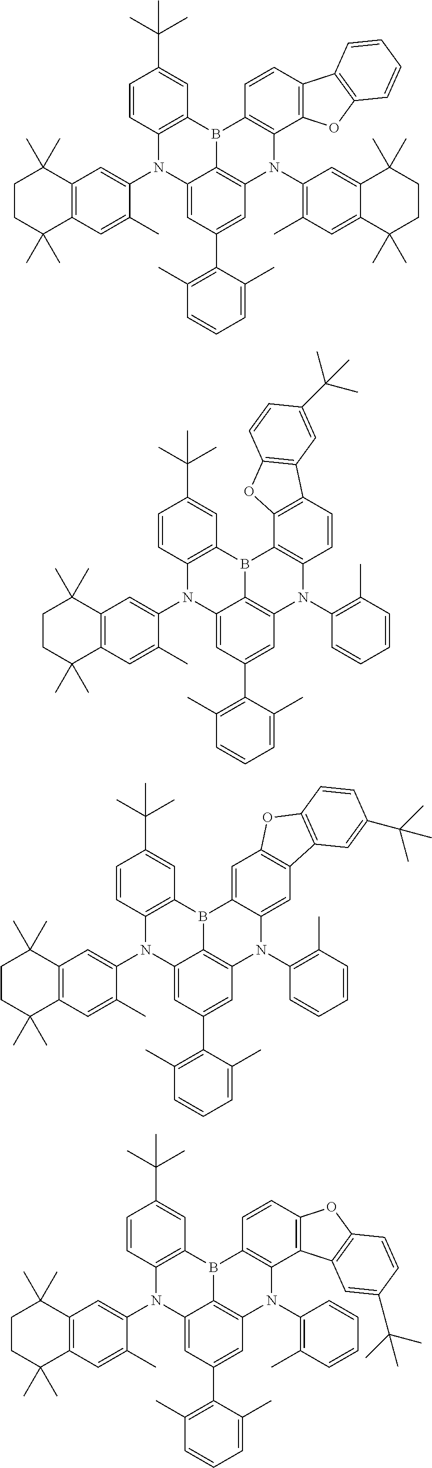

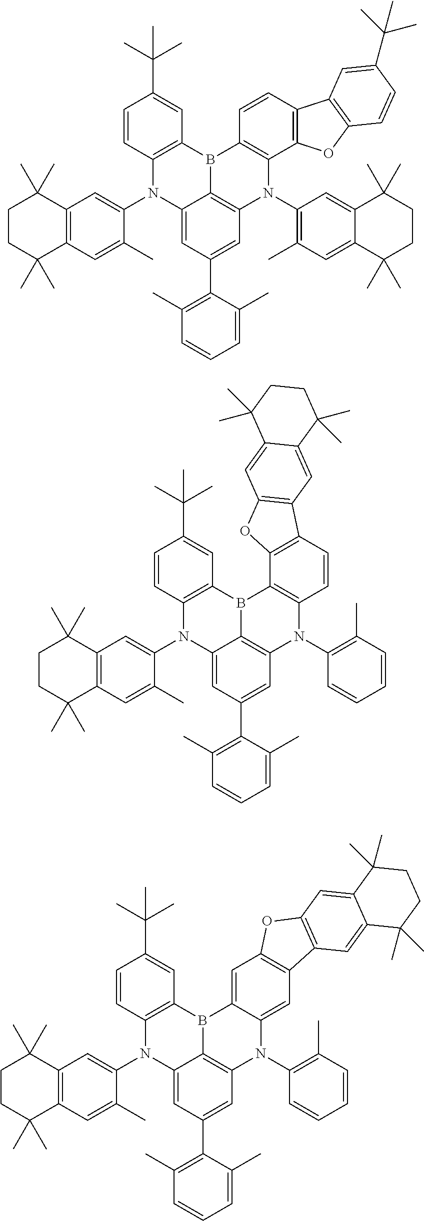

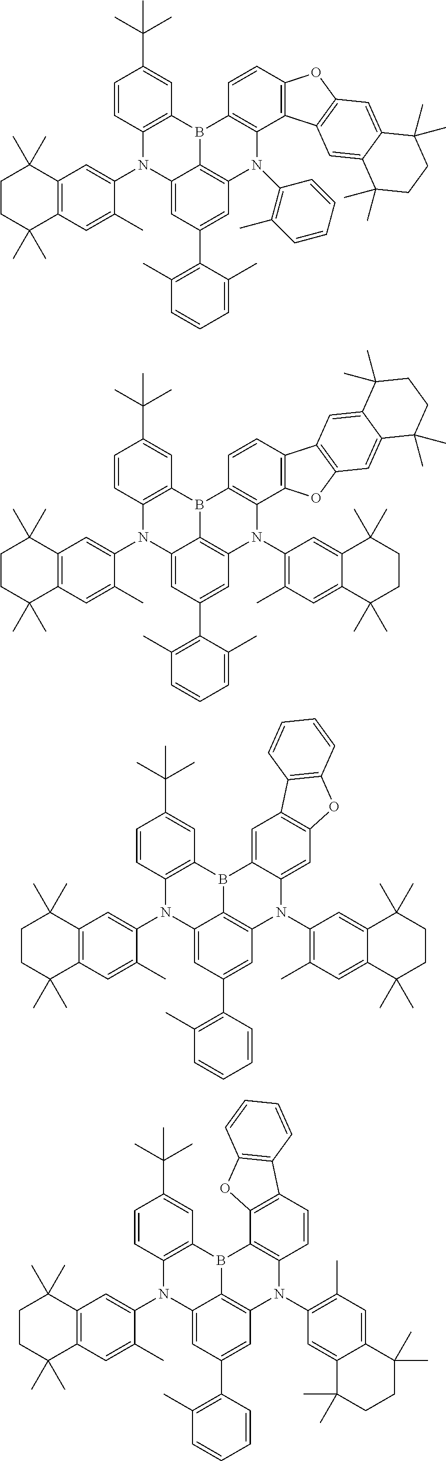

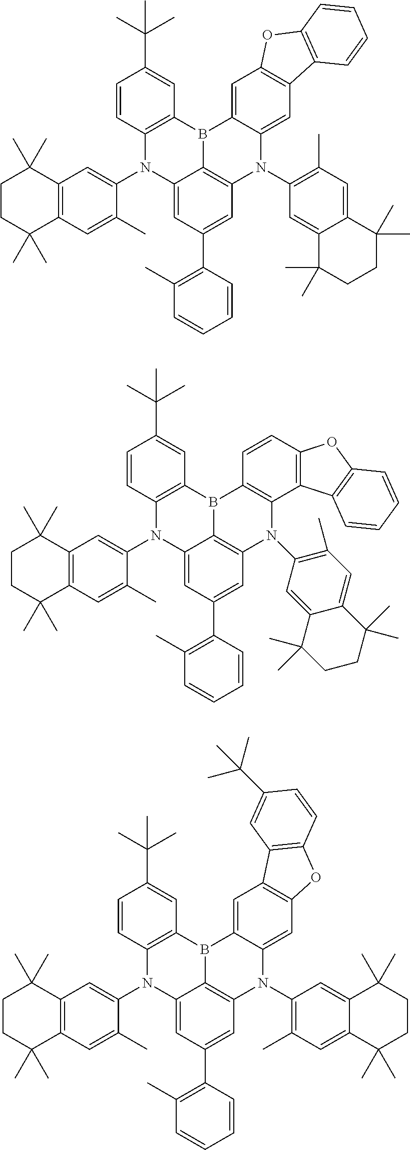

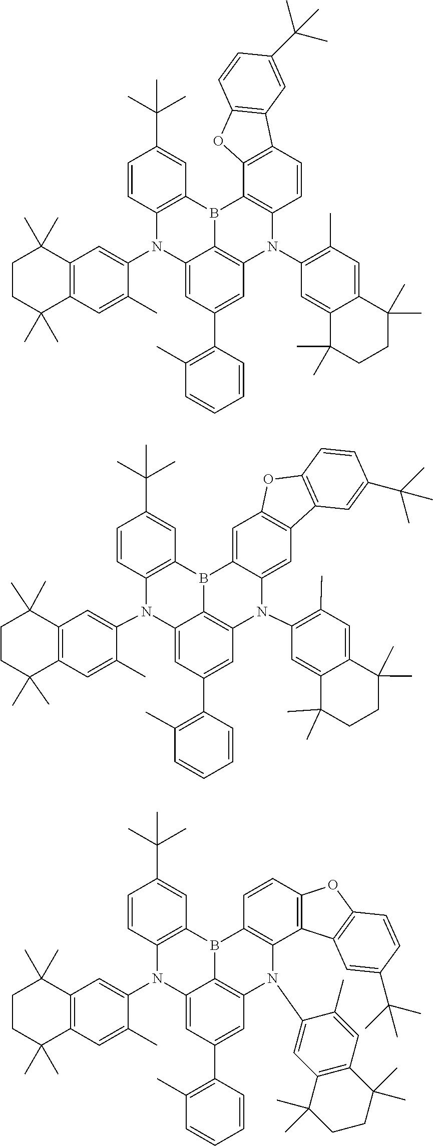 [SMILES: Cc1ccccc1-c1cc2c3c(c1)N(c1cc4c(cc1C)C(C)(C)CCC4(C)C)c1ccc4c(oc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1ccc(C(C)(C)C)cc14 ; Cc1ccccc1-c1cc2c3c(c1)N(c1cc4c(cc1C)C(C)(C)CCC4(C)C)c1c(ccc4oc5ccc(C(C)(C)C)cc5c14)B3c1cc(C(C)(C)C)ccc1N2c1cc2c(cc1C)C(C)(C)CCC2(C)C]

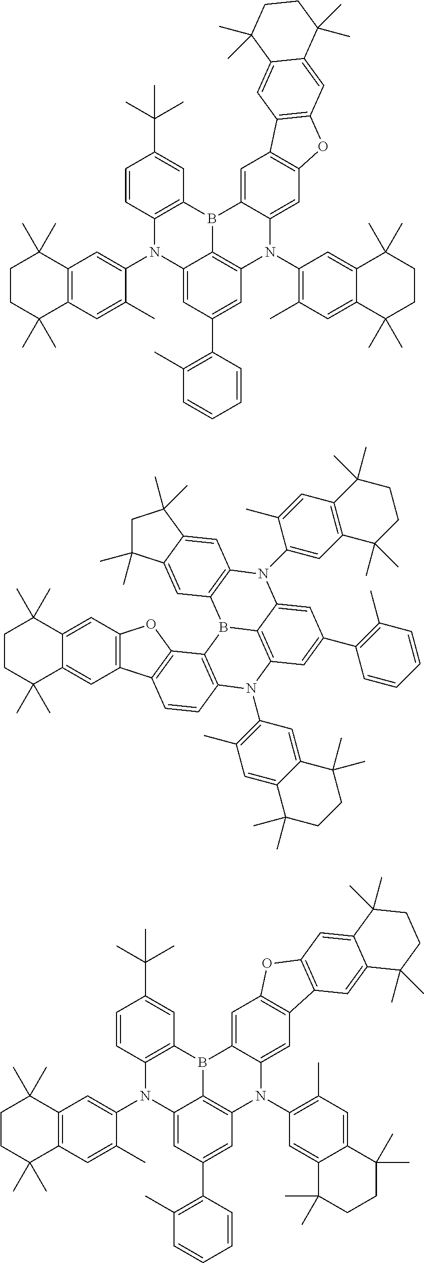 [SMILES: Cc1ccccc1-c1cc2c3c(c1)N(c1cc4c(cc1C)C(C)(C)CCC4(C)C)c1cc4oc5cc6c(cc5c4cc1B3c1cc(C(C)(C)C)ccc1N2c1cc2c(cc1C)C(C)(C)CCC2(C)C)C(C)(C)CCC6(C)C ; Cc1ccccc1-c1cc2c3c(c1)N(c1cc4c(cc1C)C(C)(C)CCC4(C)C)c1ccc4c(oc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1cc2c(cc14)C(C)(C)CCC2(C)C]

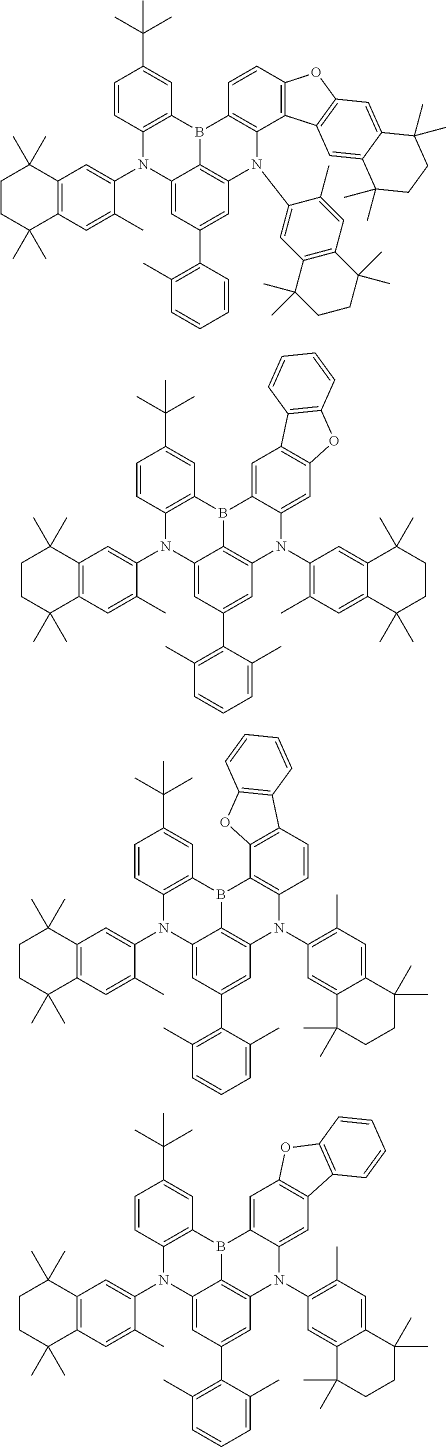

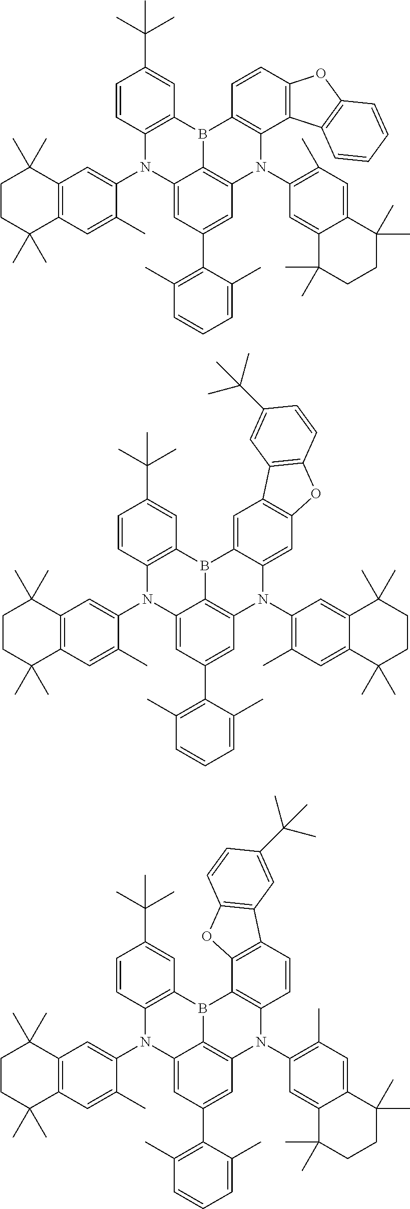

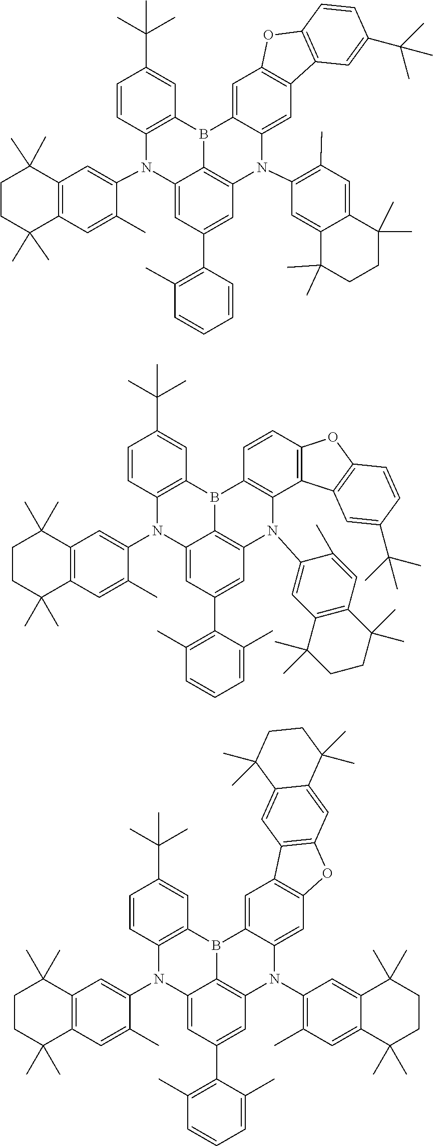 [SMILES: Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1ccc(C(C)(C)C)cc14 ; Cc1cc2c(cc1N1c3ccc(C(C)(C)C)cc3B3c4ccc5oc6ccc(C(C)(C)C)cc6c5c4N(c4cc5c(cc4C)C(C)(C)CCC5(C)C)c4cc(-c5c(C)cccc5C)cc1c43)C(C)(C)CCC2(C)C ; Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)oc1cc3c(cc15)C(C)(C)CCC3(C)C)C(C)(C)CCC2(C)C]

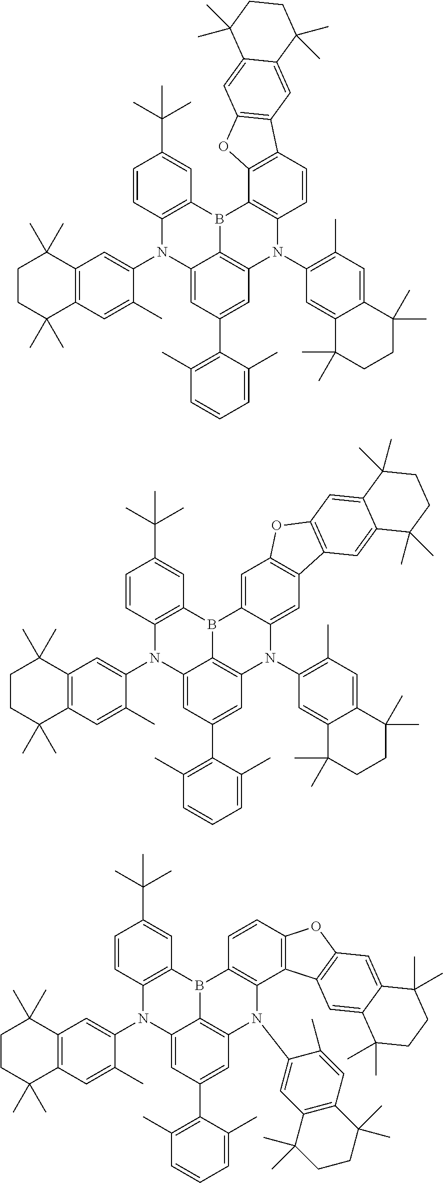 [SMILES: Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(oc5cc6c(cc54)C(C)(C)CCC6(C)C)c13)C(C)(C)CCC2(C)C ; Cc1cc2c(cc1N1c3ccc(C(C)(C)C)cc3B3c4cc5oc6cc7c(cc6c5cc4N(c4cc5c(cc4C)C(C)(C)CCC5(C)C)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5oc6cc7c(cc6c5c4N(c4cc5c(cc4C)C(C)(C)CCC5(C)C)c4cc(-c5c(C)cccc5C)cc1c43)C(C)(C)CCC7(C)C)C(C)(C)CCC2(C)C]

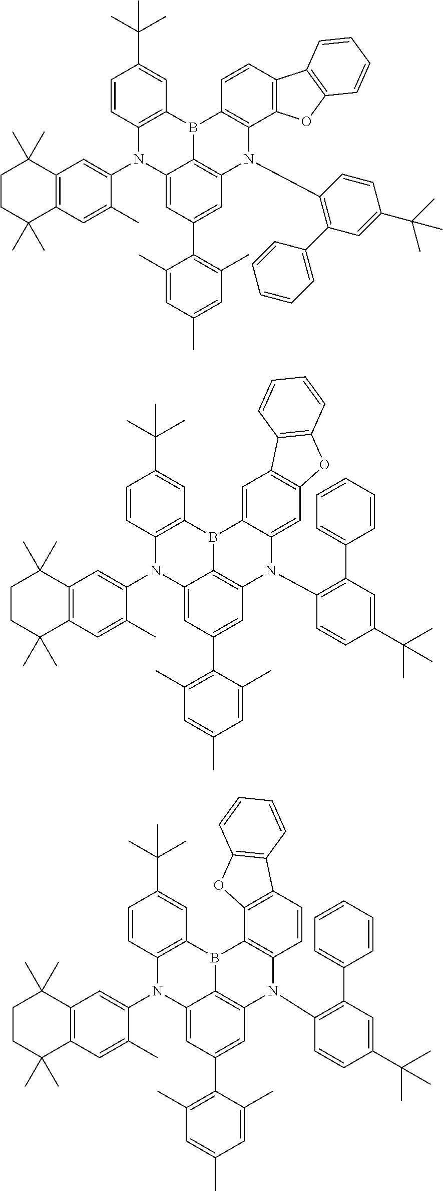

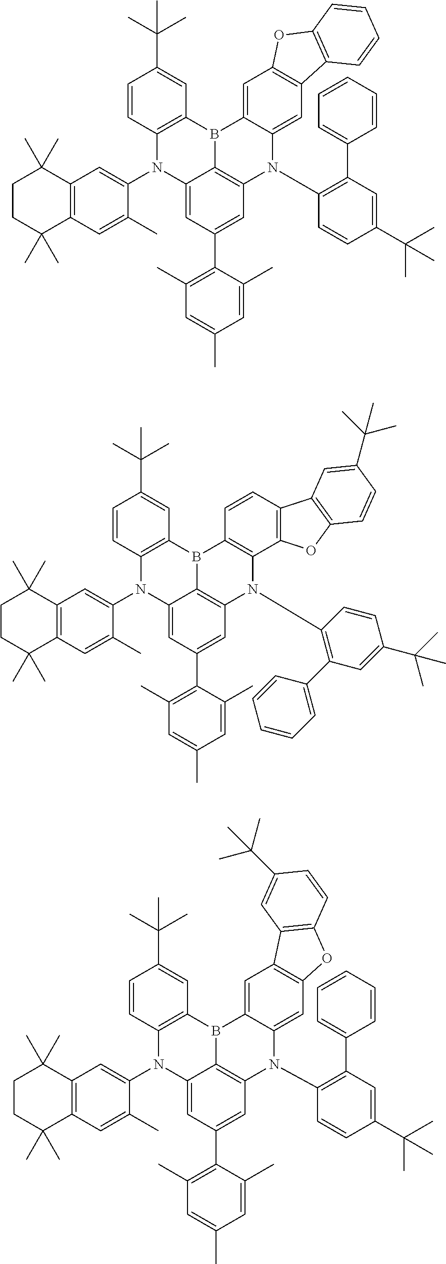 [SMILES: Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)oc2ccccc25)c(C)c1 ; Cc1cc(C)c(-c2cc3c4c(c2)N(c2ccc(C(C)(C)C)cc2-c2ccccc2)c2c(ccc5c2oc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc(C(C)(C)C)ccc2N3c2cc3c(cc2C)C(C)(C)CCC3(C)C)c(C)c1]

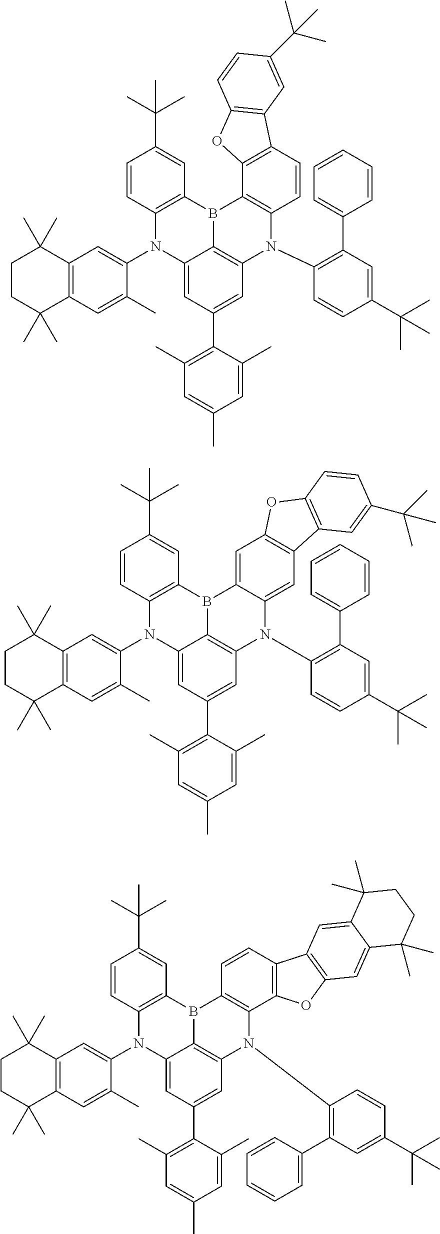 [SMILES: Cc1cc(C)c(-c2cc3c4c(c2)N(c2ccc(C(C)(C)C)cc2-c2ccccc2)c2ccc5c(oc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1]

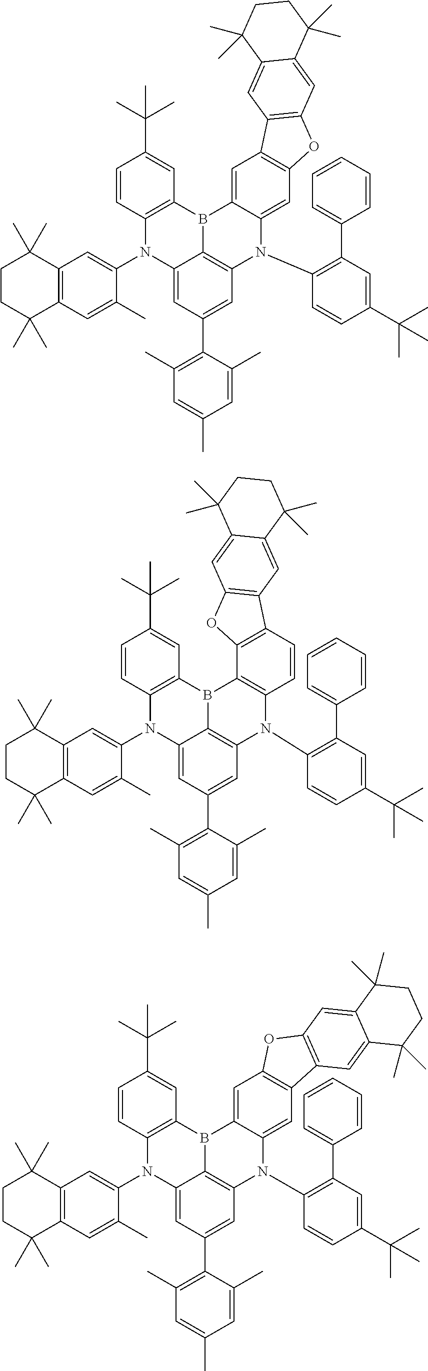

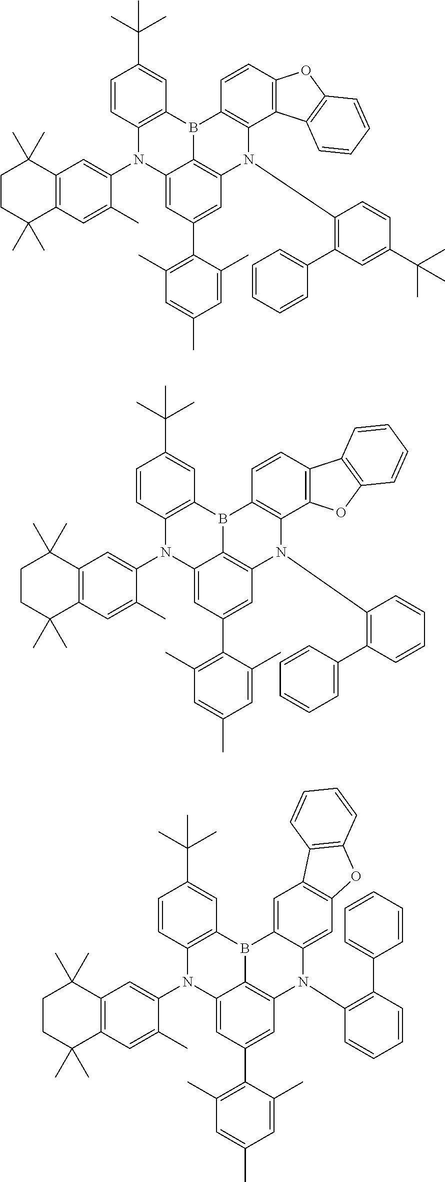

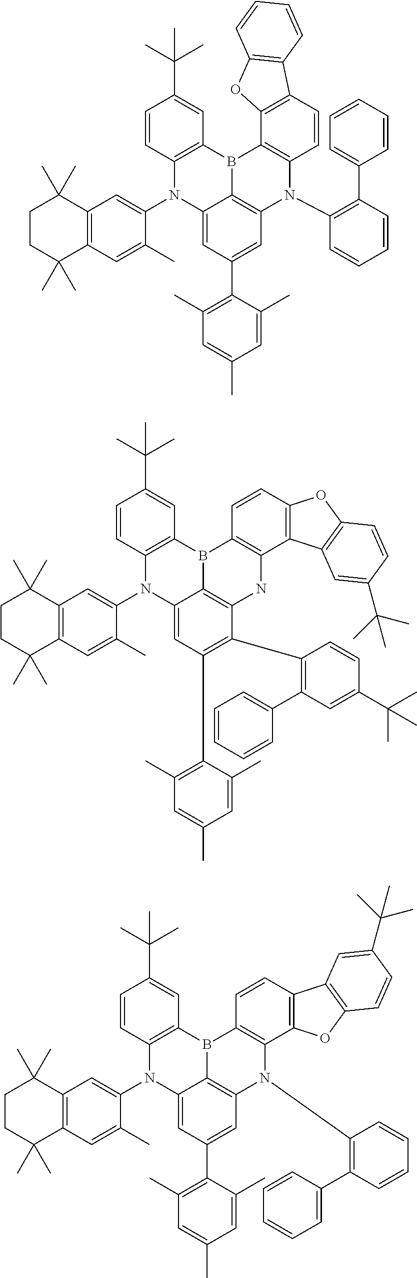 [SMILES: Cc1cc(C)c(-c2cc3c4c(c2)N(c2ccccc2-c2ccccc2)c2ccc5c(oc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2-c2ccc(C(C)(C)C)cc2-c2ccccc2)Nc2c(ccc5oc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc(C(C)(C)C)ccc2N3c2cc3c(cc2C)C(C)(C)CCC3(C)C)c(C)c1]

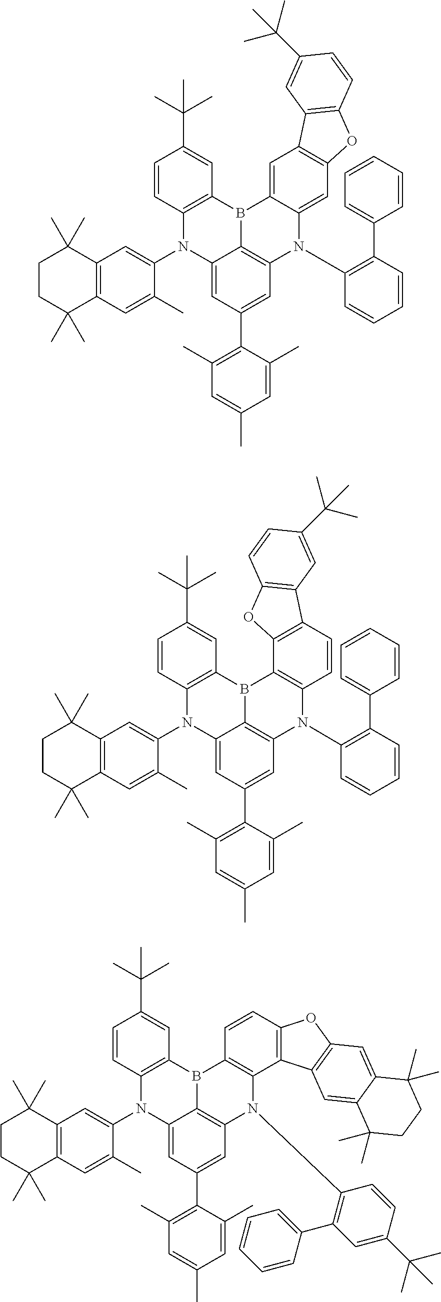 [SMILES: Cc1cc(C)c(-c2cc3c4c(c2)N(c2ccccc2-c2ccccc2)c2cc5oc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2ccc5c(oc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1]

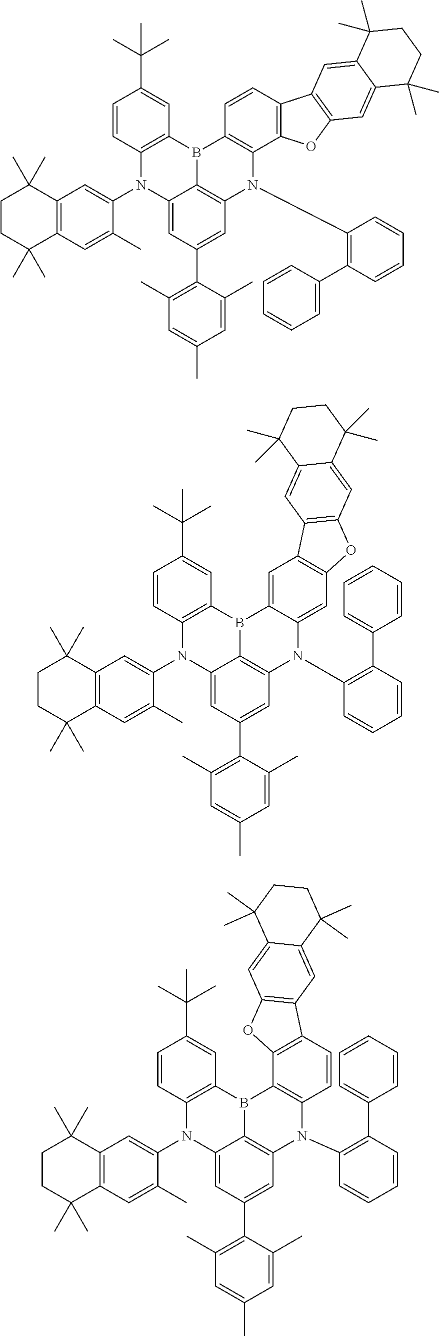

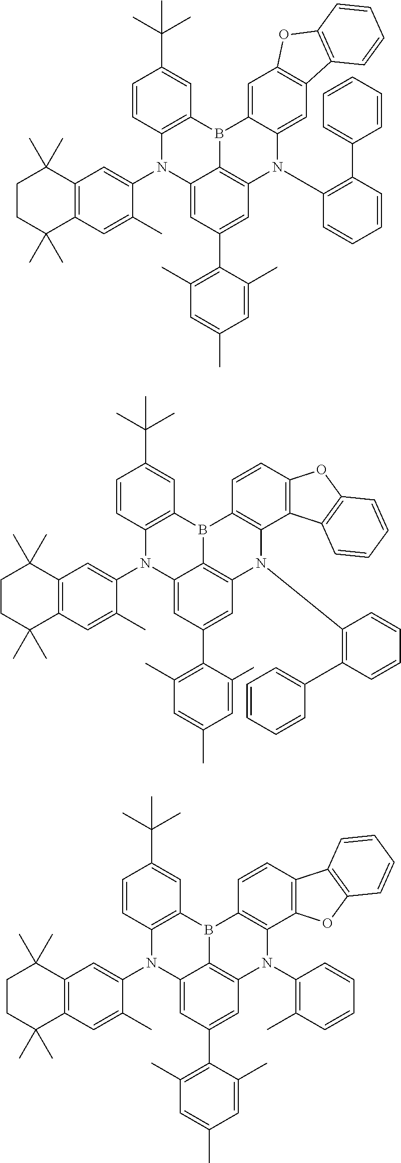 [SMILES: Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2c(ccc5c2oc2ccccc25)B4c2cc(C(C)(C)C)ccc2N3c2cc3c(cc2C)C(C)(C)CCC3(C)C)c(C)c1]

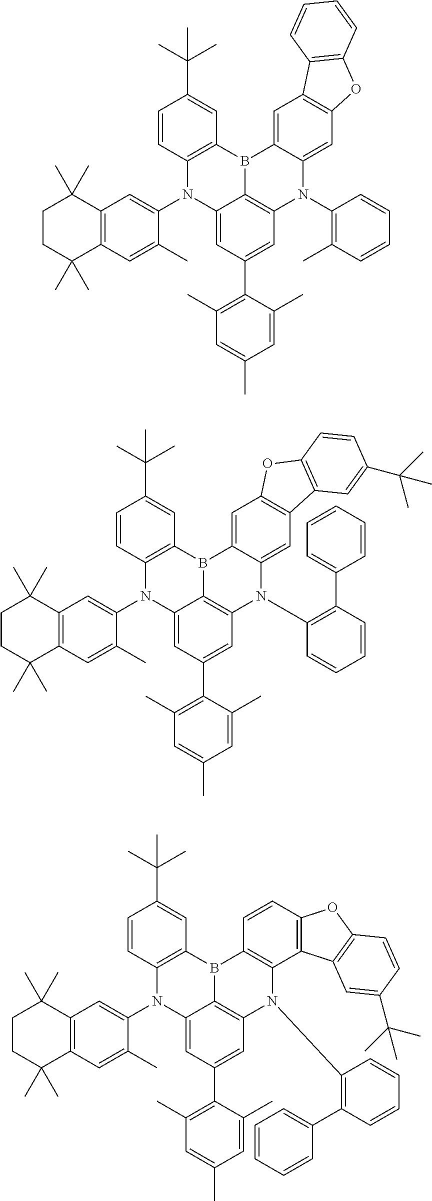 [SMILES: Cc1cc(C)c(-c2cc3c4c(c2)N(c2ccccc2C)c2cc5oc6ccccc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)oc2ccc(C(C)(C)C)cc25)c(C)c1 ; Cc1cc(C)c(-c2cc3c4c(c2)N(c2ccccc2-c2ccccc2)c2c(ccc5oc6ccc(C(C)(C)C)cc6c25)B4c2cc(C(C)(C)C)ccc2N3c2cc3c(cc2C)C(C)(C)CCC3(C)C)c(C)c1]

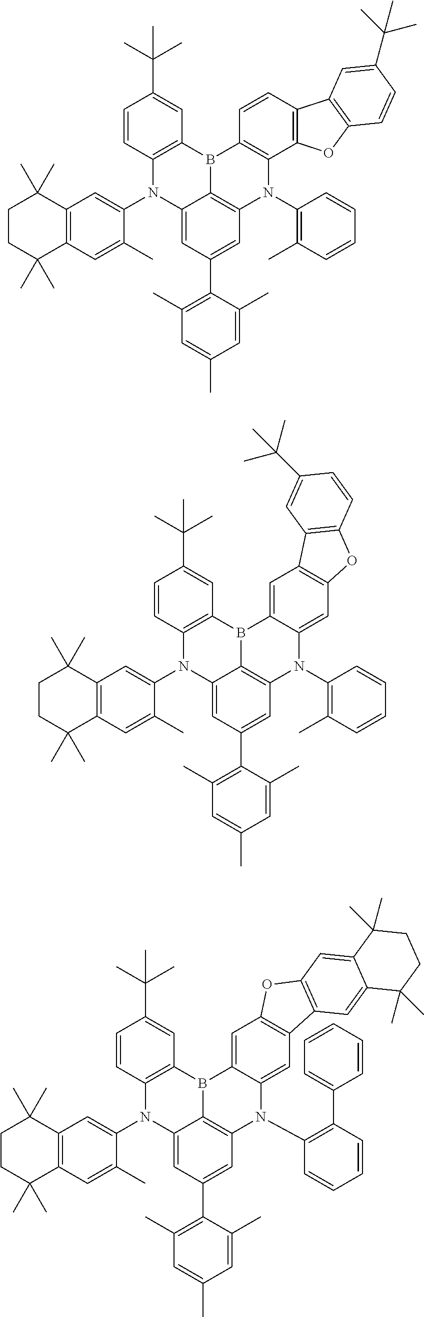 [SMILES: Cc1cc(C)c(-c2cc3c4c(c2)N(c2ccccc2C)c2c(ccc5c2oc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5oc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1]

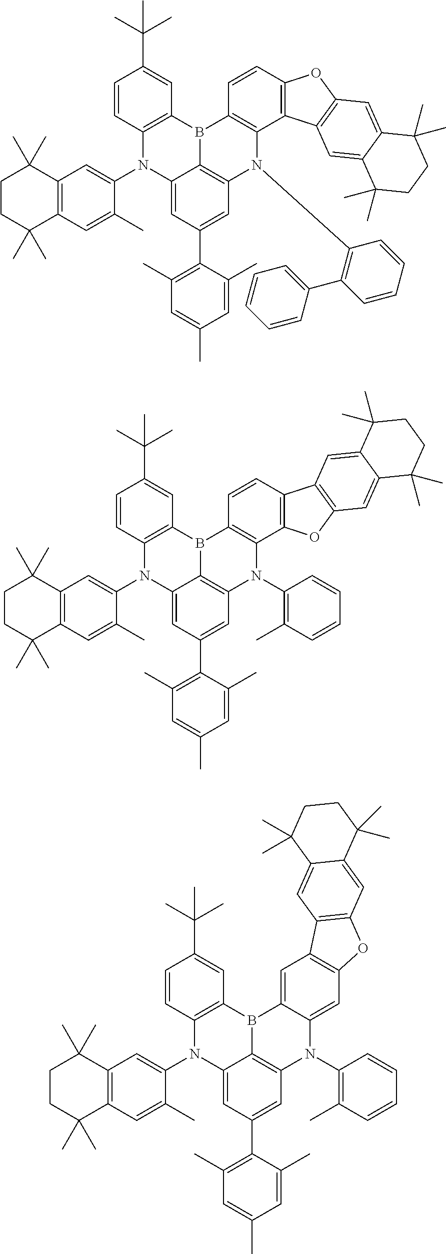 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5oc6cc7c(cc6c5cc2B4c2cc(C(C)(C)C)ccc2N3c2cc3c(cc2C)C(C)(C)CCC3(C)C)C(C)(C)CCC7(C)C)c(C)c1]

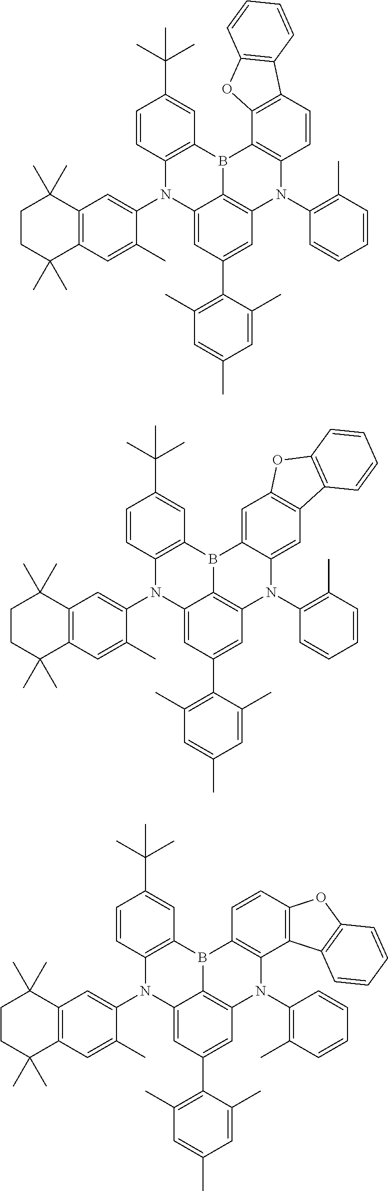 [SMILES: Cc1cc(C)c(-c2cc3c4c(c2)N(c2ccccc2C)c2ccc5c(oc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)oc2ccccc25)c(C)c1 ; Cc1cc(C)c(-c2cc3c4c(c2)N(c2ccccc2C)c2c(ccc5oc6ccccc6c25)B4c2cc(C(C)(C)C)ccc2N3c2cc3c(cc2C)C(C)(C)CCC3(C)C)c(C)c1]

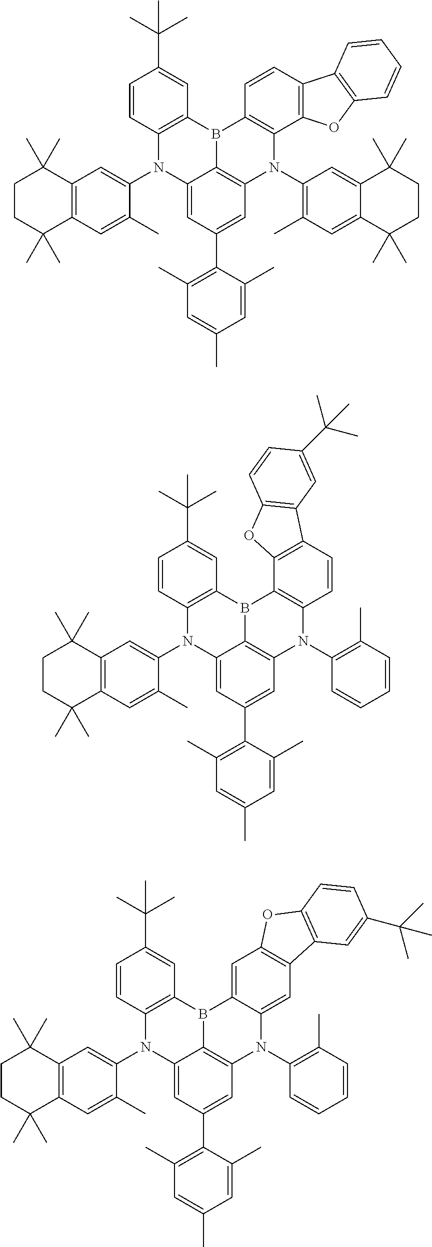 [SMILES: Cc1cc(C)c(-c2cc3c4c(c2)N(c2cc5c(cc2C)C(C)(C)CCC5(C)C)c2c(ccc5c2oc2ccccc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2ccc5c(oc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)oc2ccc(C(C)(C)C)cc25)c(C)c1]

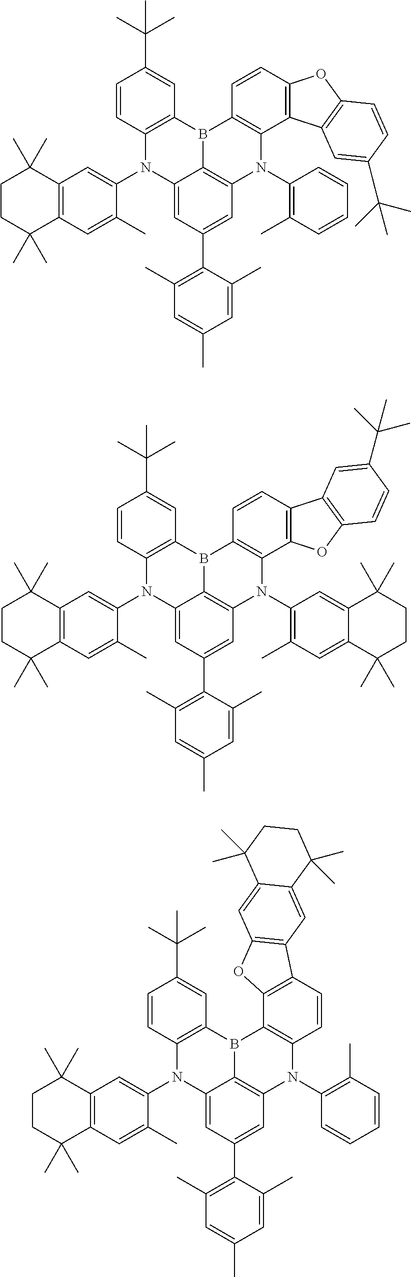

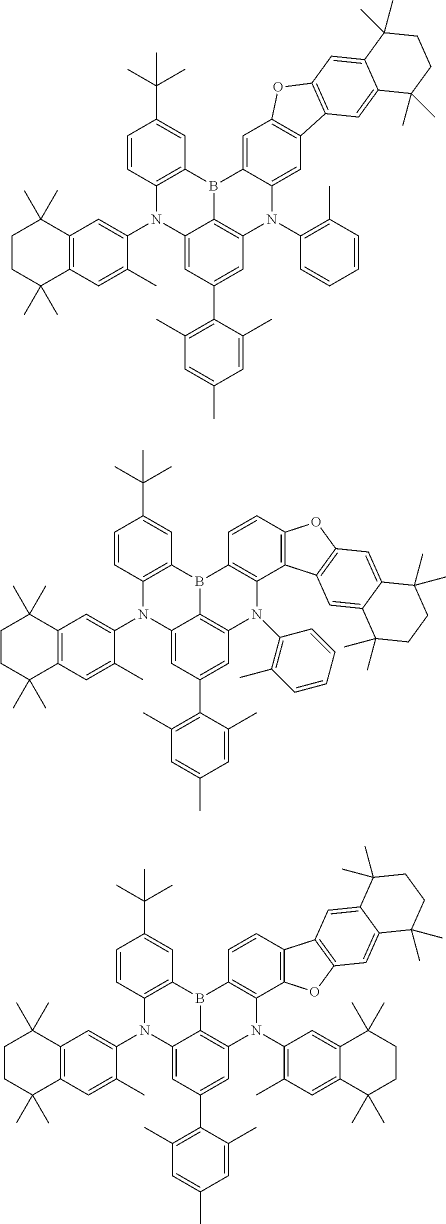 [SMILES: Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1]

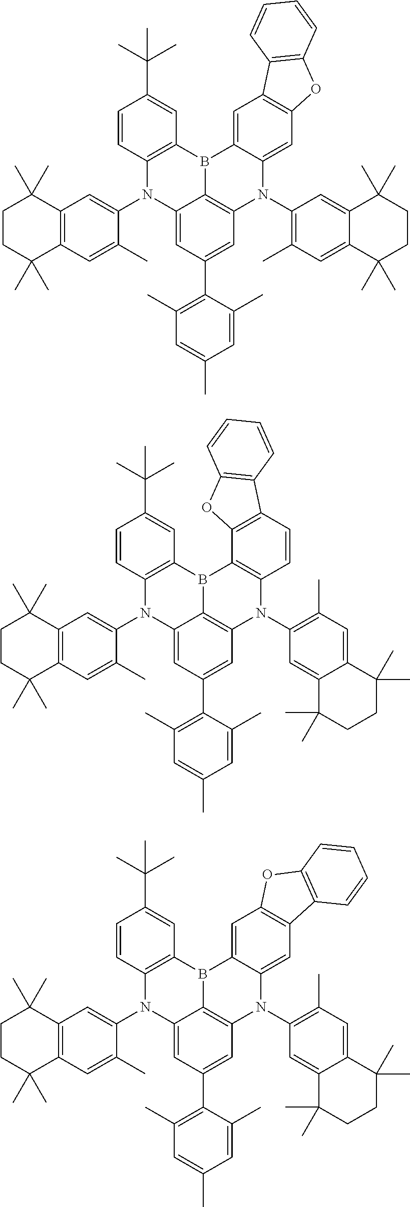

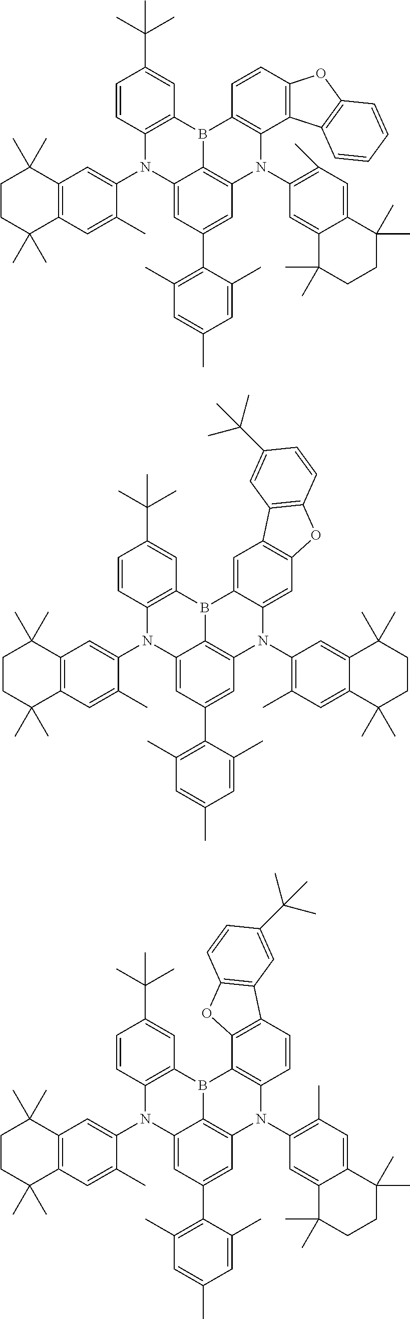

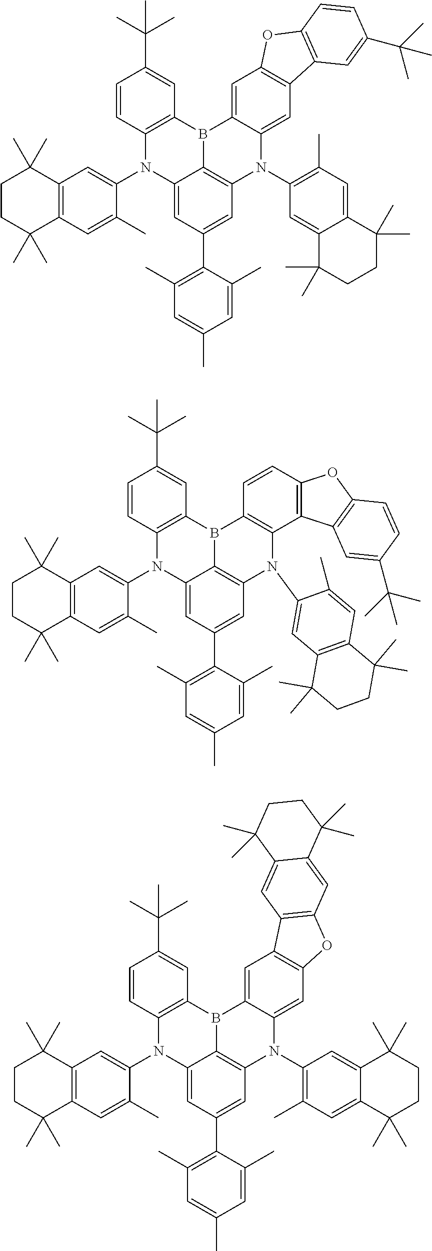 [SMILES: Cc1cc(C)c(-c2cc3c4c(c2)N(c2cc5c(cc2C)C(C)(C)CCC5(C)C)c2cc5c(cc2B4c2cc(C(C)(C)C)ccc2N3c2cc3c(cc2C)C(C)(C)CCC3(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc(C(C)(C)C)ccc2N3c2cc3c(cc2C)C(C)(C)CCC3(C)C)C(C)(C)CCC7(C)C)c(C)c1]

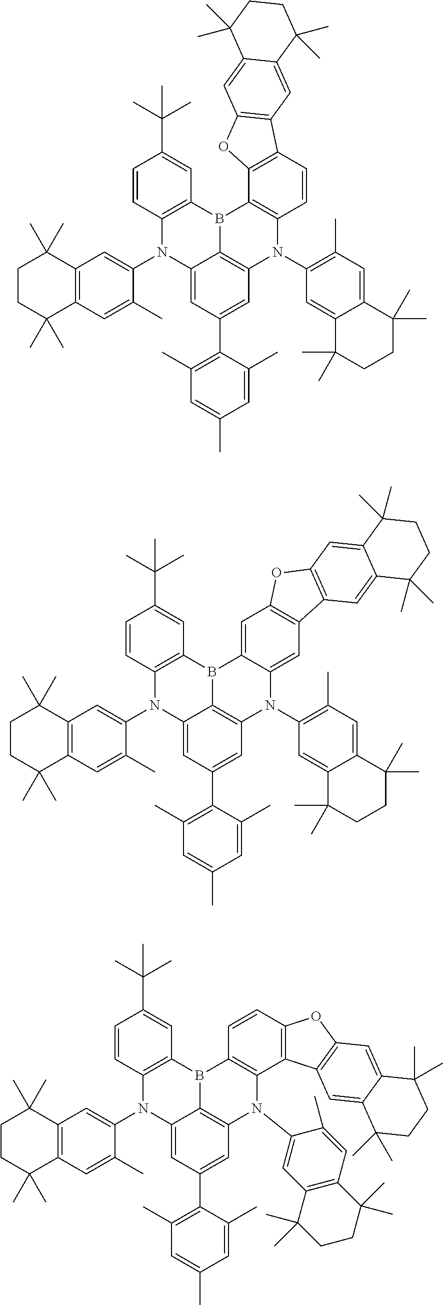 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1]

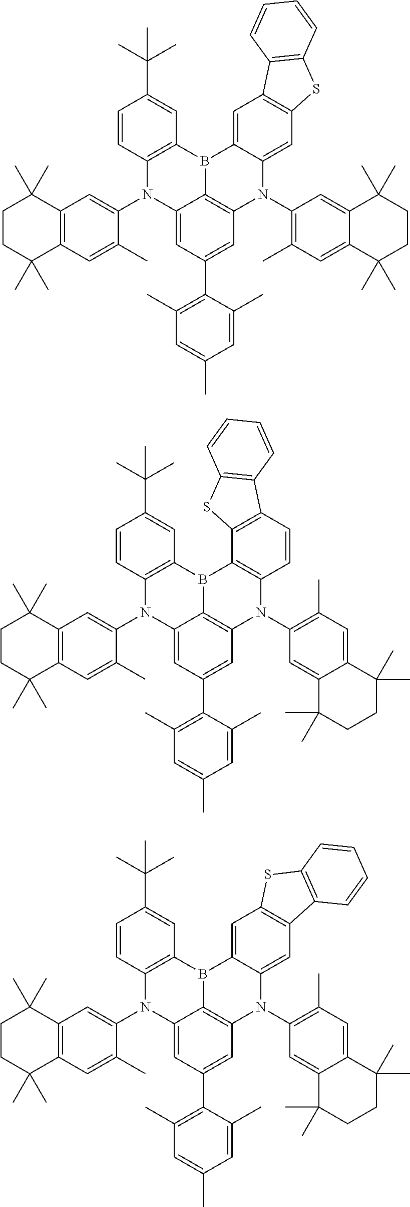

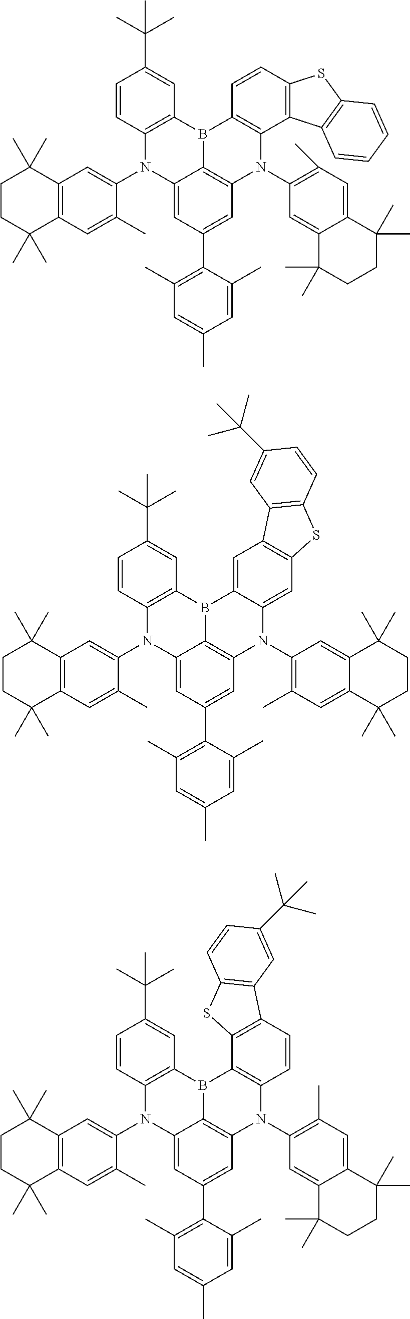

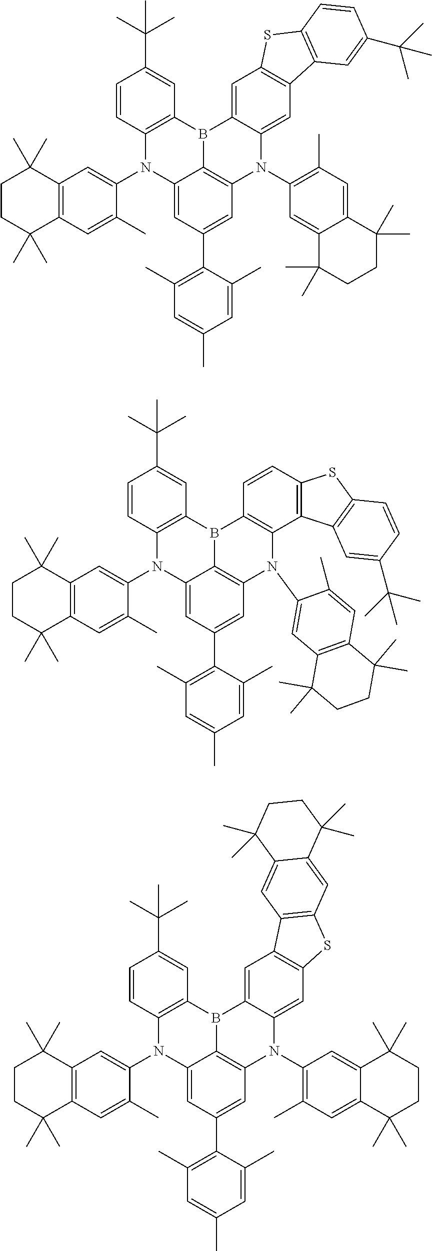 [SMILES: Cc1cc(C)c(-c2cc3c4c(c2)N(c2cc5c(cc2C)C(C)(C)CCC5(C)C)c2cc5c(cc2B4c2cc(C(C)(C)C)ccc2N3c2cc3c(cc2C)C(C)(C)CCC3(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2cc5sc6cc7c(cc6c5cc2B4c2cc(C(C)(C)C)ccc2N3c2cc3c(cc2C)C(C)(C)CCC3(C)C)C(C)(C)CCC7(C)C)c(C)c1]

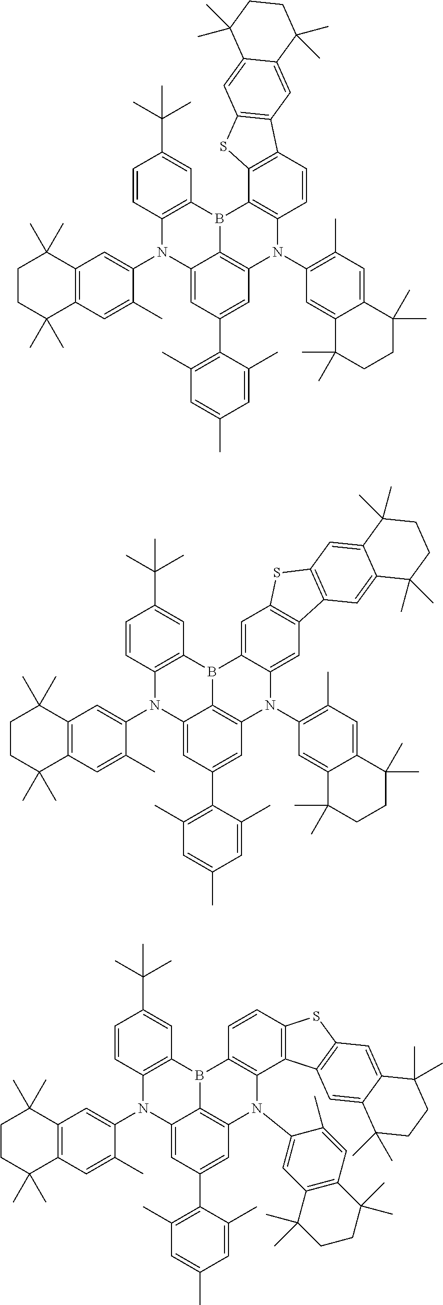 [SMILES: Cc1cc(C)c(-c2cc3c4c(c2)N(c2cc5c(cc2C)C(C)(C)CCC5(C)C)c2ccc5c(sc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2cc5c(cc2B4c2cc(C(C)(C)C)ccc2N3c2cc3c(cc2C)C(C)(C)CCC3(C)C)sc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5sc6cc7c(cc6c25)C(C)(C)CCC7(C)C)B4c2cc(C(C)(C)C)ccc2N3c2cc3c(cc2C)C(C)(C)CCC3(C)C)c(C)c1]

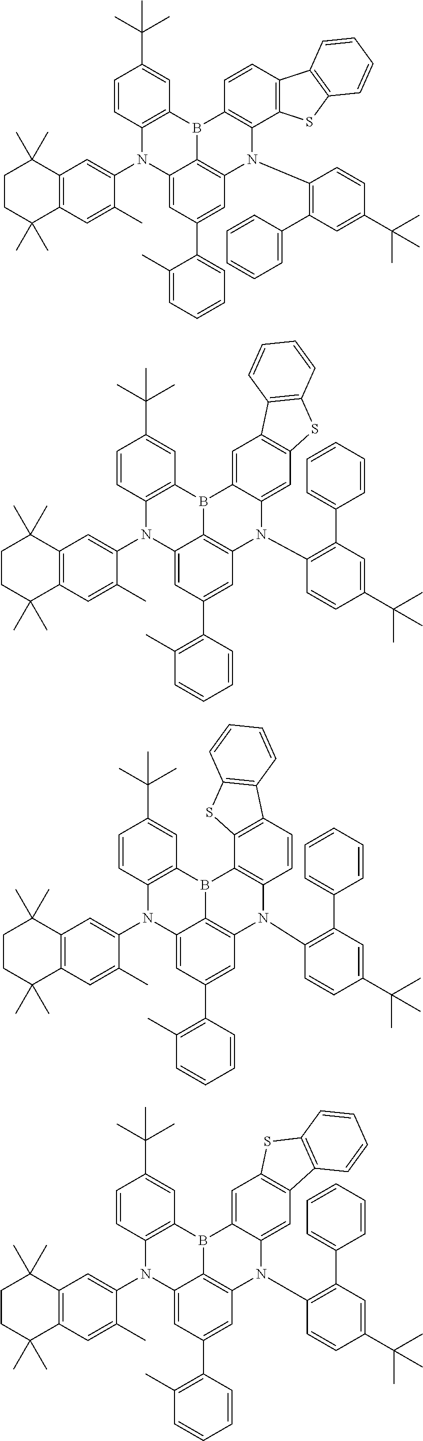

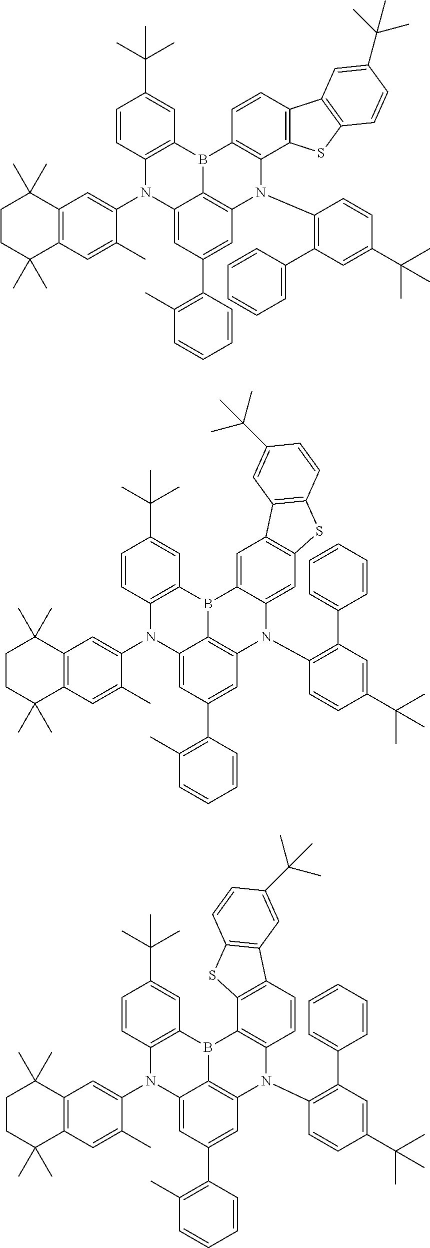

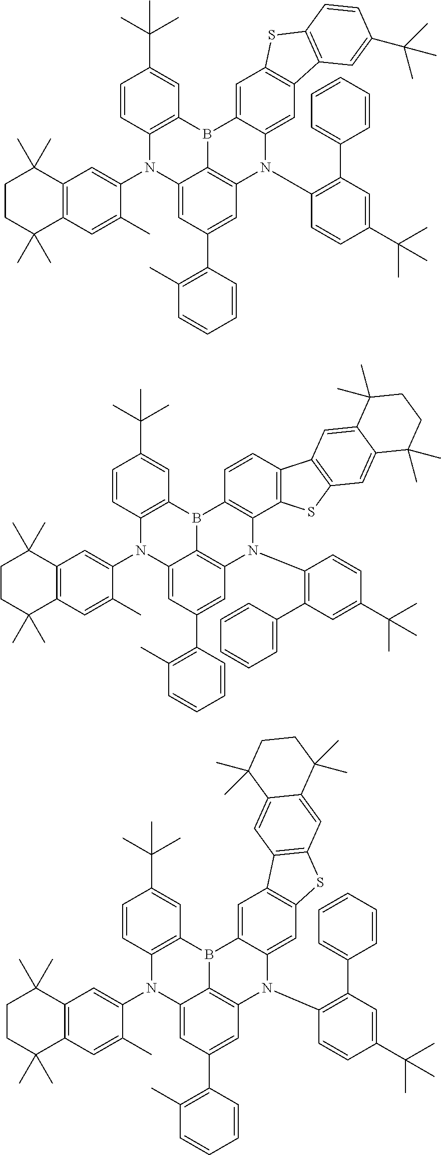 [SMILES: Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)sc1ccc(C(C)(C)C)cc14 ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4sc5cc6c(cc5c4cc1B3c1cc(C(C)(C)C)ccc1N2c1cc2c(cc1C)C(C)(C)CCC2(C)C)C(C)(C)CCC6(C)C]

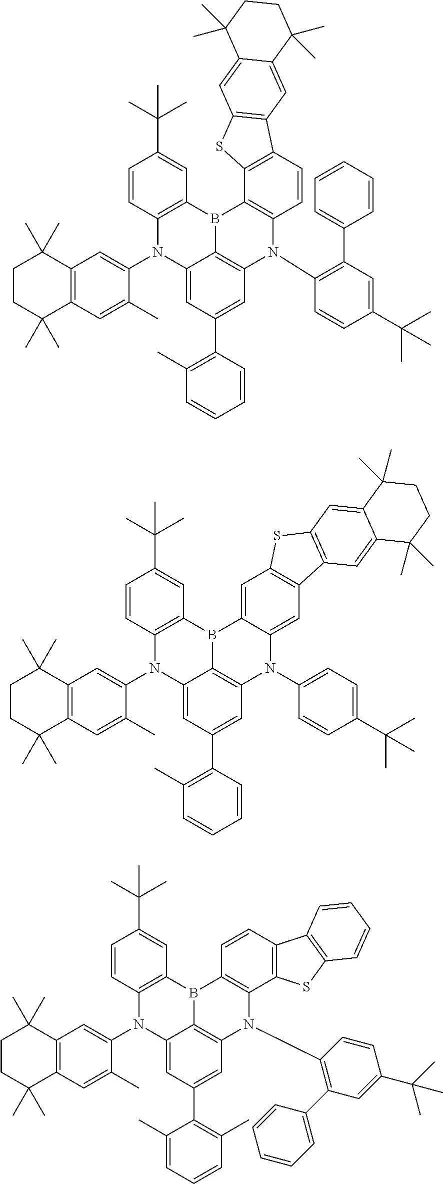 [SMILES: Cc1ccccc1-c1cc2c3c(c1)N(c1ccc(C(C)(C)C)cc1-c1ccccc1)c1ccc4c(sc5cc6c(cc54)C(C)(C)CCC6(C)C)c1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1ccc(C(C)(C)C)cc1B3c1cc3sc4cc5c(cc4c3cc1N2c1ccc(C(C)(C)C)cc1)C(C)(C)CCC5(C)C ; Cc1cc2c(cc1N1c3ccc(C(C)(C)C)cc3B3c4ccc5c(sc6ccccc65)c4N(c4ccc(C(C)(C)C)cc4-c4ccccc4)c4cc(-c5c(C)cccc5C)cc1c43)C(C)(C)CCC2(C)C]

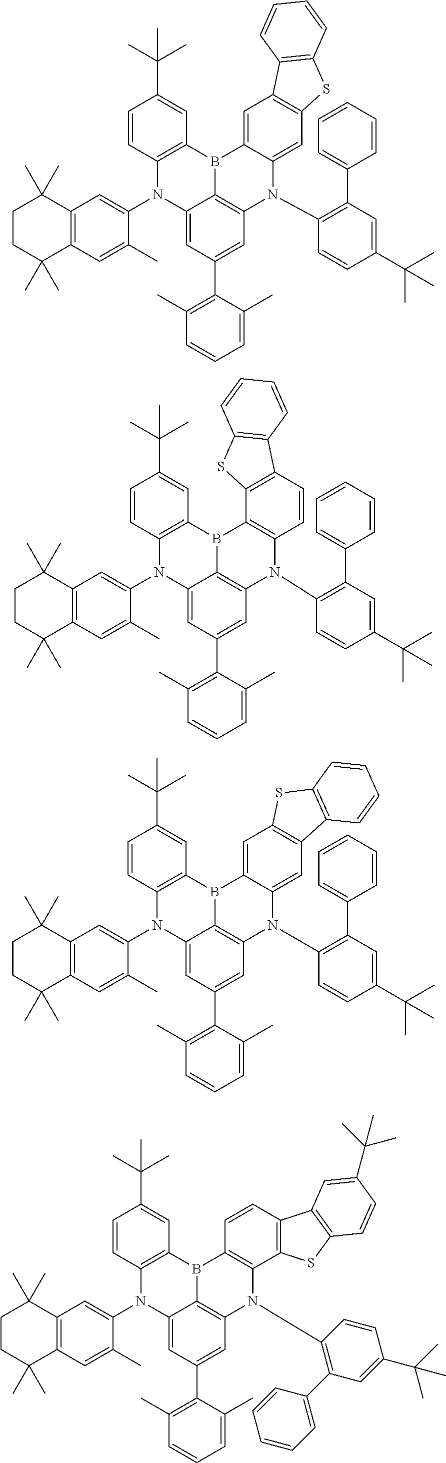

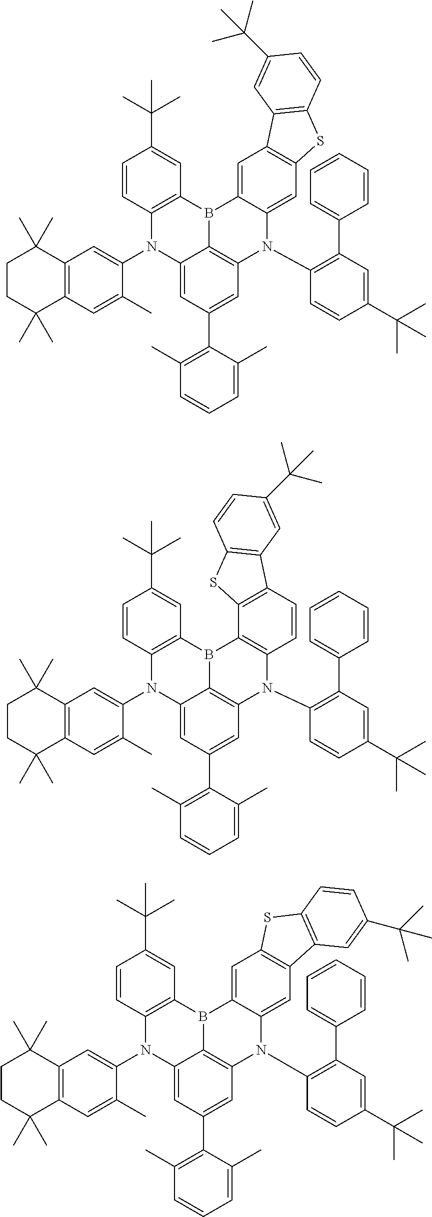 [SMILES: Cc1cc2c(cc1N1c3ccc(C(C)(C)C)cc3B3c4cc5c(cc4N(c4ccc(C(C)(C)C)cc4-c4ccccc4)c4cc(-c6c(C)cccc6C)cc1c43)sc1ccc(C(C)(C)C)cc15)C(C)(C)CCC2(C)C ; Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4cc5sc6ccc(C(C)(C)C)cc6c5cc4N(c4ccc(C(C)(C)C)cc4-c4ccccc4)c4cc(-c5c(C)cccc5C)cc1c43)C(C)(C)CCC2(C)C]

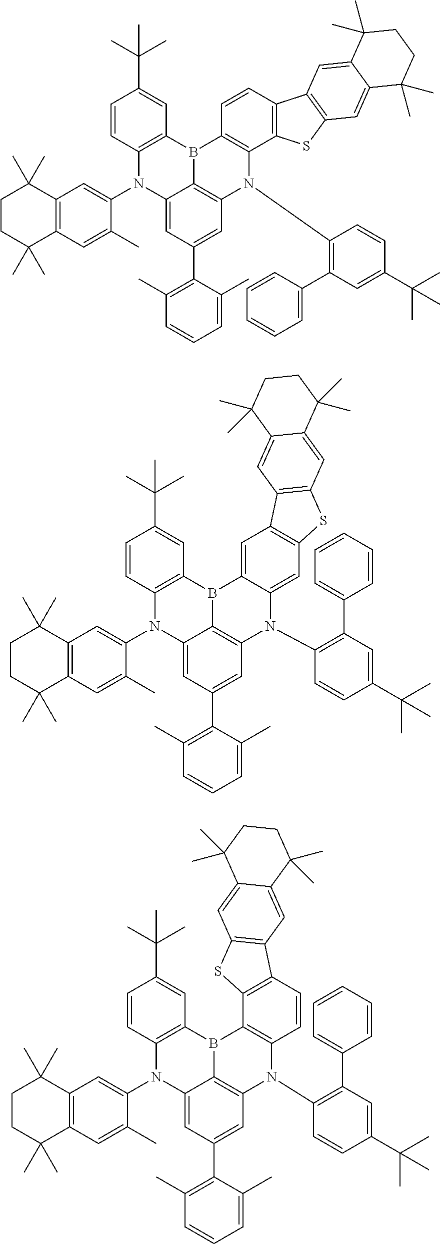

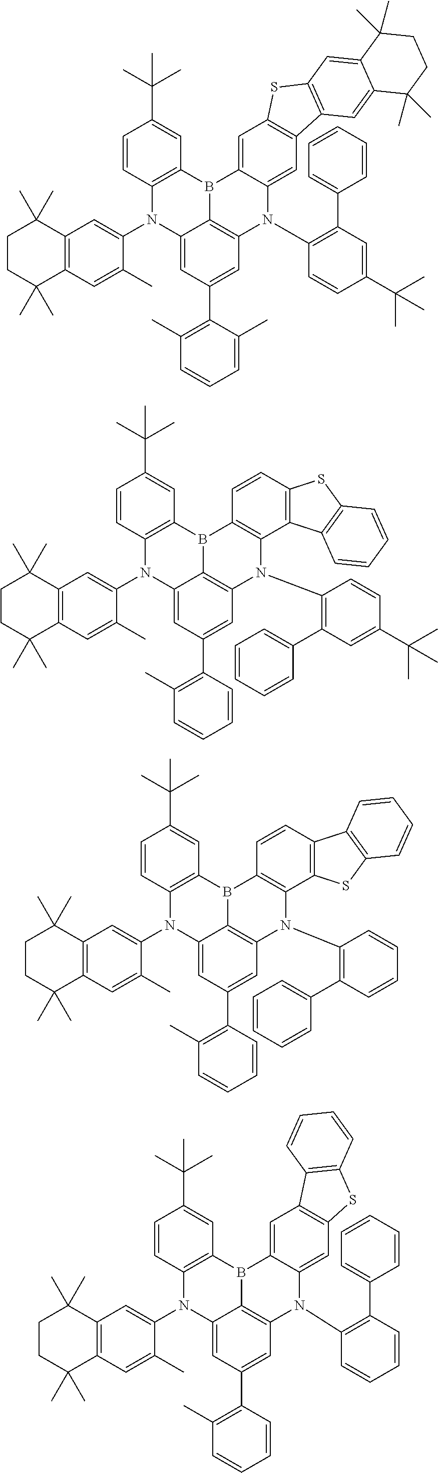

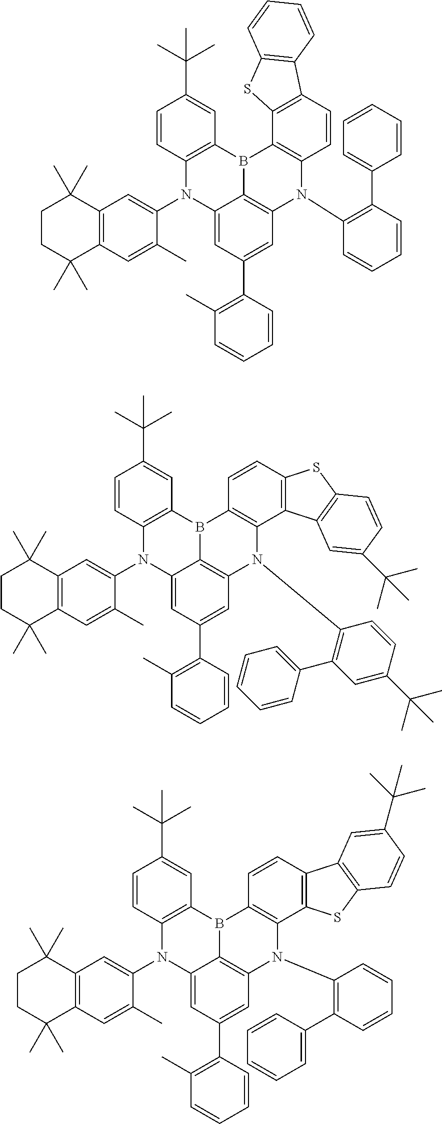

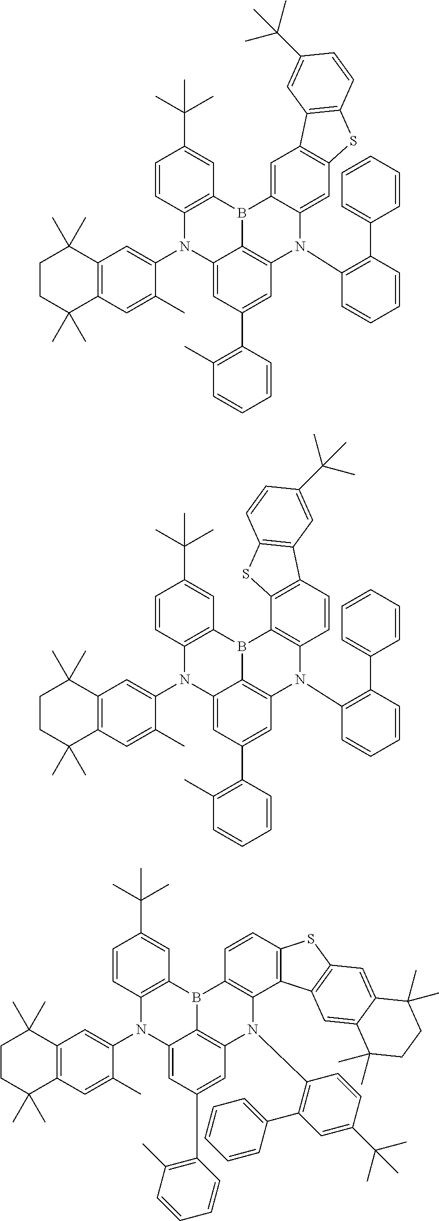 [SMILES: Cc1ccccc1-c1cc2c3c(c1)N(c1ccccc1-c1ccccc1)c1cc4sc5ccc(C(C)(C)C)cc5c4cc1B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1ccc4c(sc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1c(ccc4sc5cc6c(cc5c14)C(C)(C)CCC6(C)C)B3c1cc(C(C)(C)C)ccc1N2c1cc2c(cc1C)C(C)(C)CCC2(C)C]

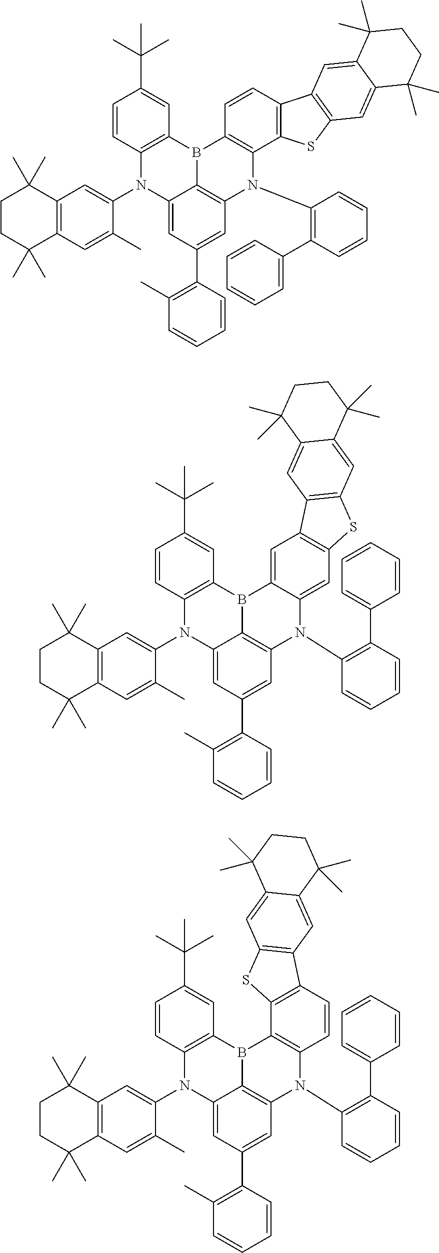

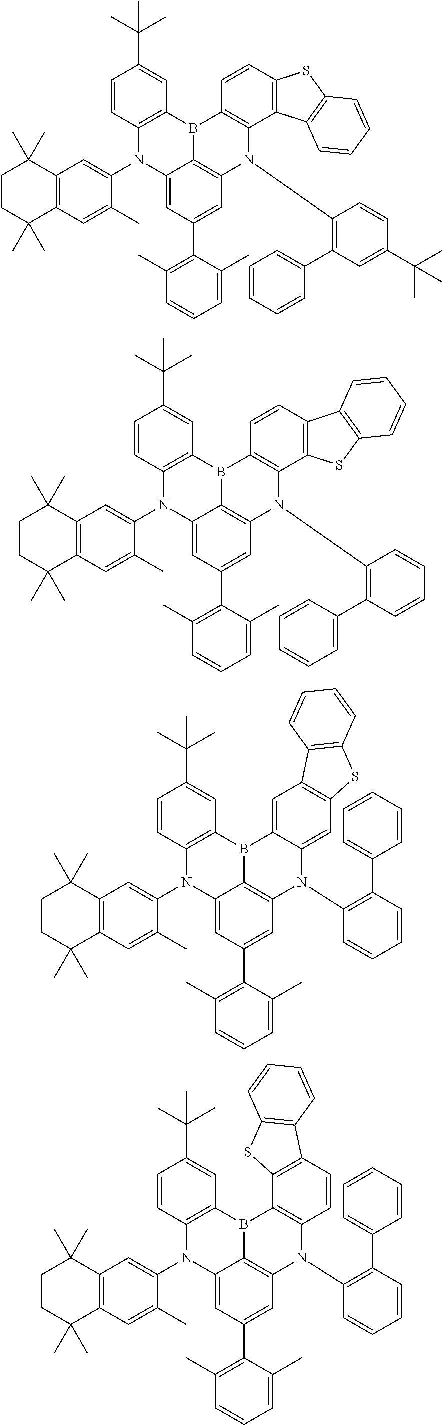

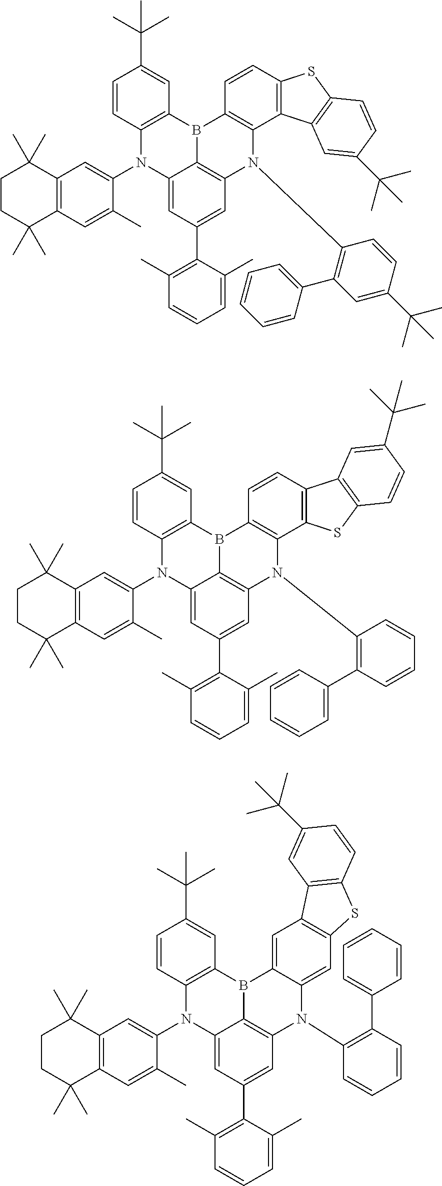

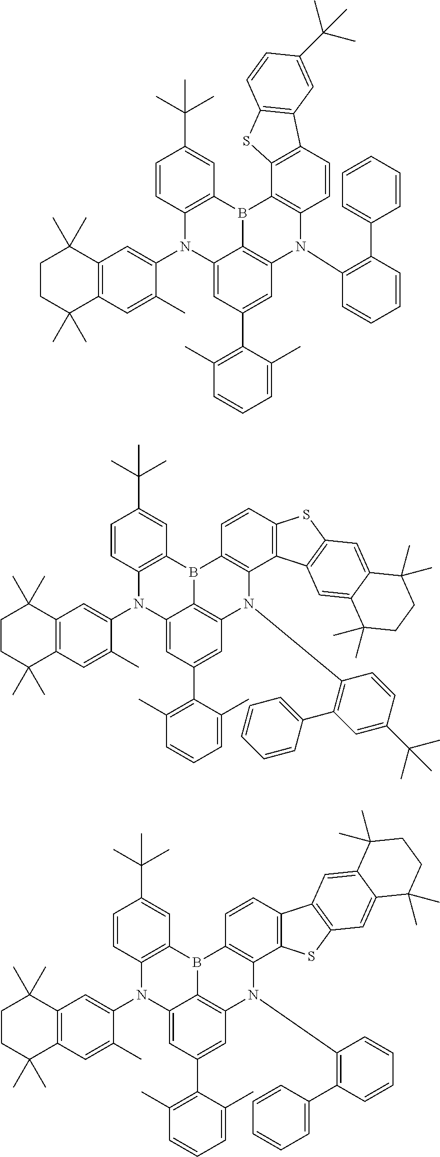 [SMILES: Cc1cc2c(cc1N1c3ccc(C(C)(C)C)cc3B3c4c1cc(-c1c(C)cccc1C)cc4N(c1ccccc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4ccc5sc6cc7c(cc6c5c4N(c4ccc(C(C)(C)C)cc4-c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccccc4-c4ccccc4)c4cc(-c5c(C)cccc5C)cc1c43)C(C)(C)CCC2(C)C]

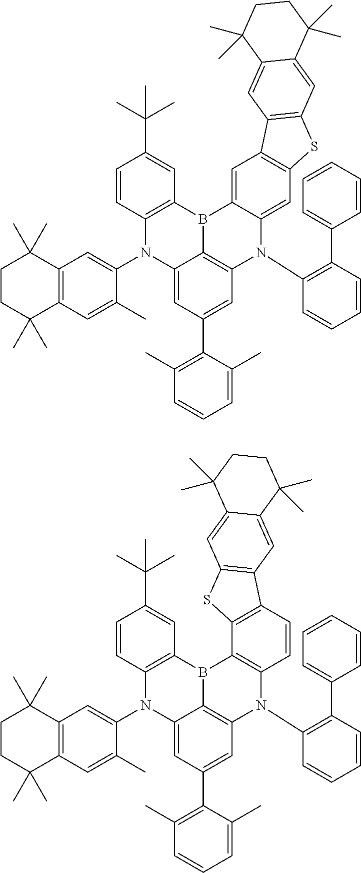

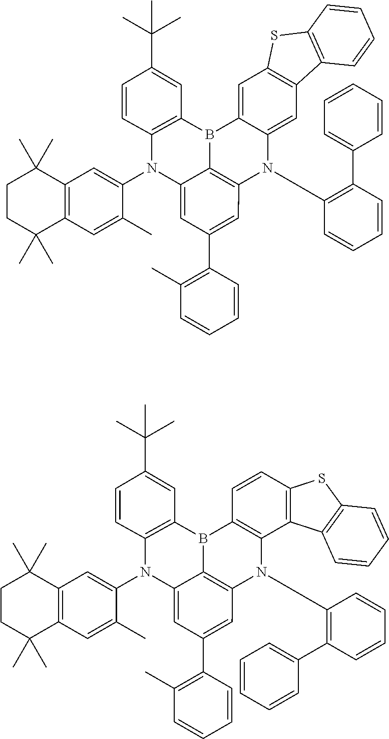 [SMILES: Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1ccccc14 ; Cc1ccccc1-c1cc2c3c(c1)N(c1ccccc1-c1ccccc1)c1c(ccc4sc5ccccc5c14)B3c1cc(C(C)(C)C)ccc1N2c1cc2c(cc1C)C(C)(C)CCC2(C)C]

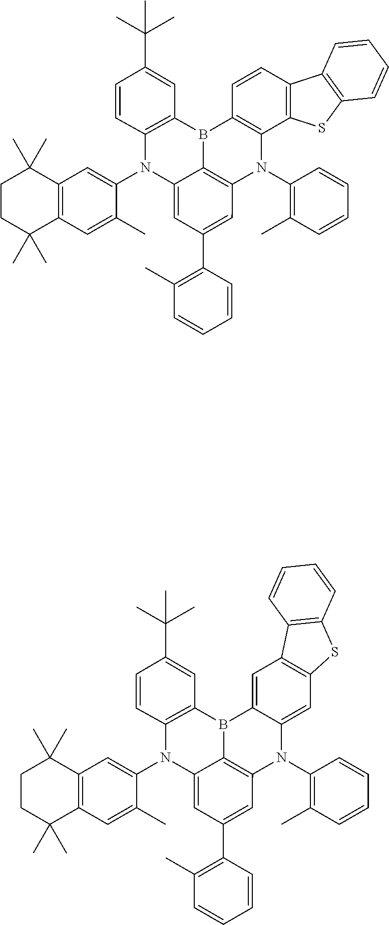 [SMILES: Cc1ccccc1-c1cc2c3c(c1)N(c1ccccc1C)c1c(ccc4c1sc1ccccc14)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4sc5ccccc5c4cc1B3c1cc(C(C)(C)C)ccc1N2c1cc2c(cc1C)C(C)(C)CCC2(C)C]

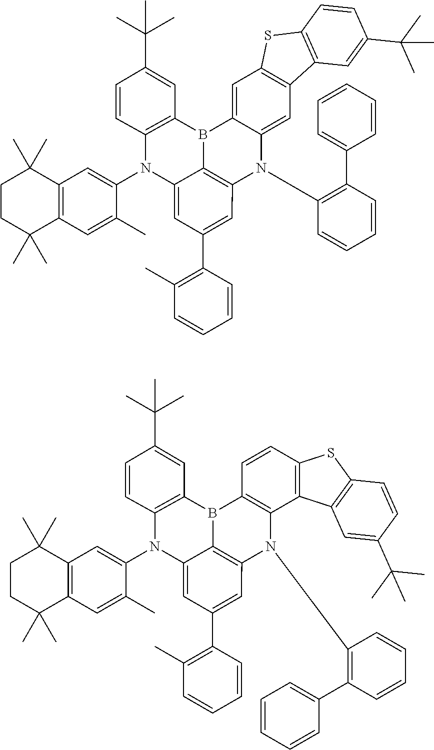 [SMILES: Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1ccc(C(C)(C)C)cc14 ; Cc1ccccc1-c1cc2c3c(c1)N(c1ccccc1-c1ccccc1)c1c(ccc4sc5ccc(C(C)(C)C)cc5c14)B3c1cc(C(C)(C)C)ccc1N2c1cc2c(cc1C)C(C)(C)CCC2(C)C]

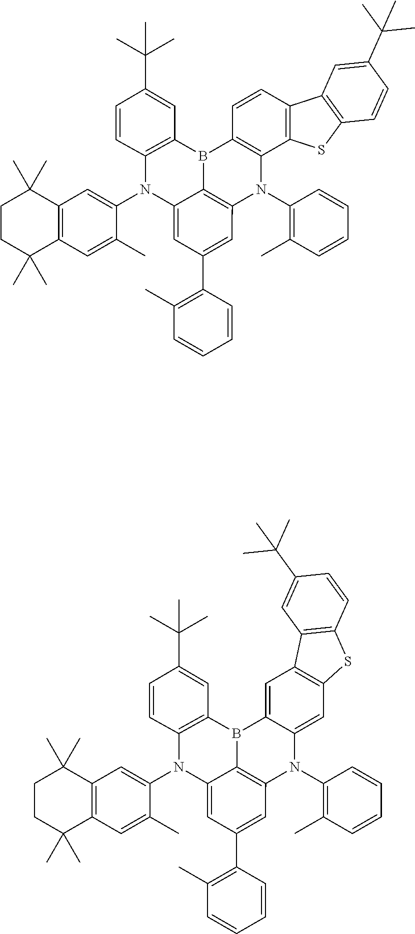 [SMILES: Cc1ccccc1-c1cc2c3c(c1)N(c1ccccc1C)c1c(ccc4c1sc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4sc5ccc(C(C)(C)C)cc5c4cc1B3c1cc(C(C)(C)C)ccc1N2c1cc2c(cc1C)C(C)(C)CCC2(C)C]

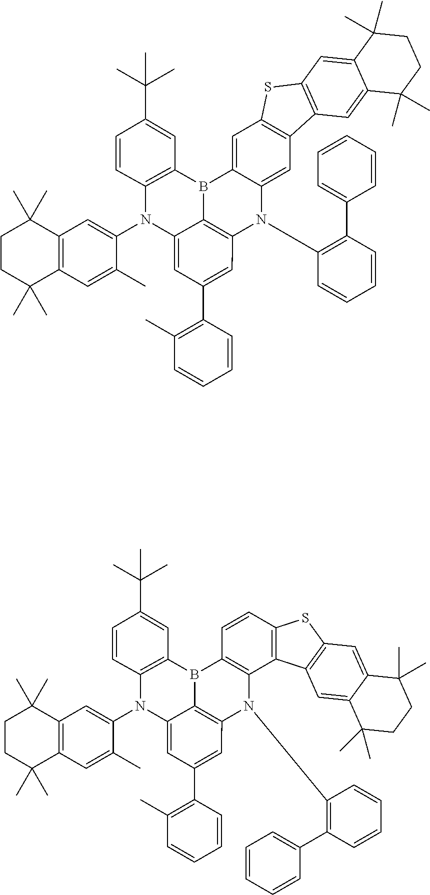 [SMILES: Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1ccccc1-c1cc2c3c(c1)N(c1ccccc1-c1ccccc1)c1c(ccc4sc5cc6c(cc5c14)C(C)(C)CCC6(C)C)B3c1cc(C(C)(C)C)ccc1N2c1cc2c(cc1C)C(C)(C)CCC2(C)C]

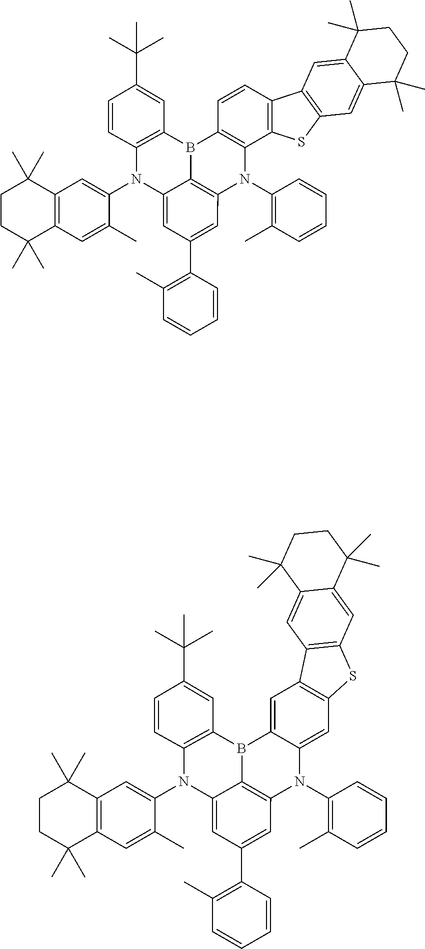 [SMILES: Cc1ccccc1-c1cc2c3c(c1)N(c1ccccc1C)c1c(ccc4c1sc1cc5c(cc14)C(C)(C)CCC5(C)C)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4sc5cc6c(cc5c4cc1B3c1cc(C(C)(C)C)ccc1N2c1cc2c(cc1C)C(C)(C)CCC2(C)C)C(C)(C)CCC6(C)C]

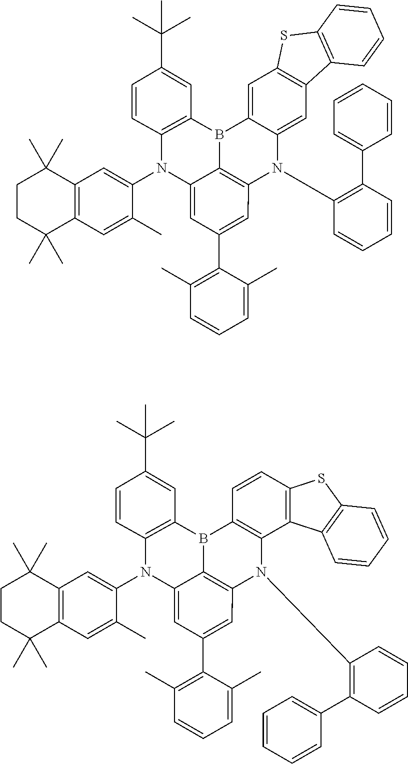 [SMILES: Cc1cc2c(cc1N1c3ccc(C(C)(C)C)cc3B3c4cc5sc6ccccc6c5cc4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5sc6ccccc6c5c4N(c4ccccc4-c4ccccc4)c4cc(-c5c(C)cccc5C)cc1c43)C(C)(C)CCC2(C)C]

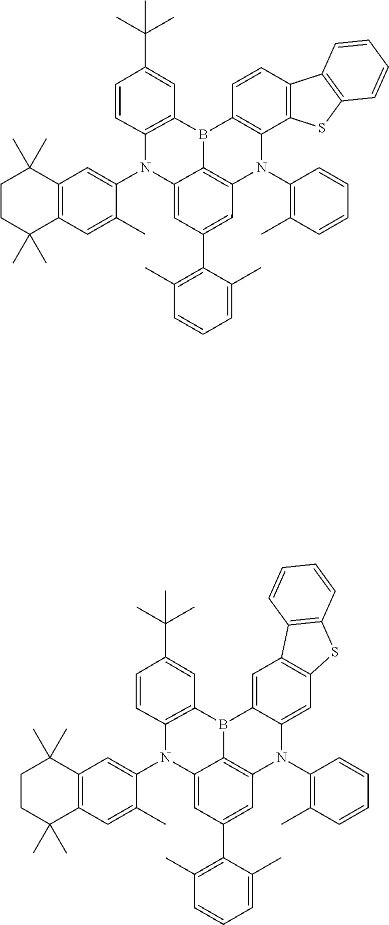 [SMILES: Cc1cc2c(cc1N1c3ccc(C(C)(C)C)cc3B3c4ccc5c(sc6ccccc65)c4N(c4ccccc4C)c4cc(-c5c(C)cccc5C)cc1c43)C(C)(C)CCC2(C)C ; Cc1ccccc1N1c2cc3sc4ccccc4c3cc2B2c3cc(C(C)(C)C)ccc3N(c3cc4c(cc3C)C(C)(C)CCC4(C)C)c3cc(-c4c(C)cccc4C)cc1c32]

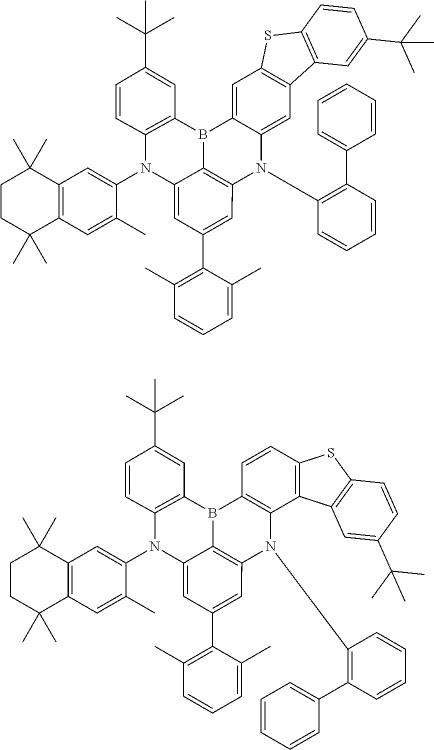 [SMILES: Cc1cc2c(cc1N1c3ccc(C(C)(C)C)cc3B3c4cc5sc6ccc(C(C)(C)C)cc6c5cc4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5sc6ccc(C(C)(C)C)cc6c5c4N(c4ccccc4-c4ccccc4)c4cc(-c5c(C)cccc5C)cc1c43)C(C)(C)CCC2(C)C]

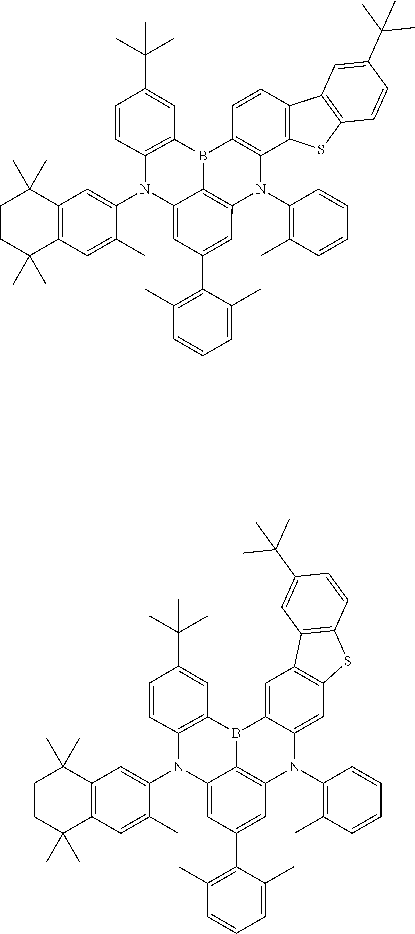 [SMILES: Cc1cc2c(cc1N1c3ccc(C(C)(C)C)cc3B3c4ccc5c(sc6ccc(C(C)(C)C)cc65)c4N(c4ccccc4C)c4cc(-c5c(C)cccc5C)cc1c43)C(C)(C)CCC2(C)C ; Cc1ccccc1N1c2cc3sc4ccc(C(C)(C)C)cc4c3cc2B2c3cc(C(C)(C)C)ccc3N(c3cc4c(cc3C)C(C)(C)CCC4(C)C)c3cc(-c4c(C)cccc4C)cc1c32]

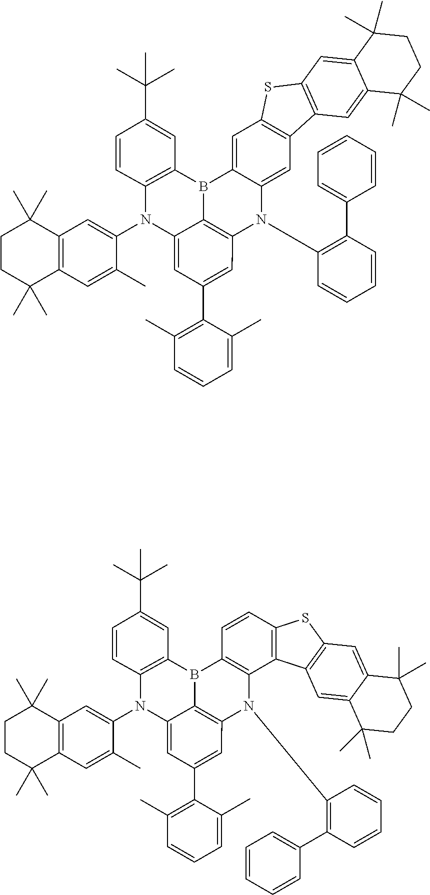 [SMILES: Cc1cc2c(cc1N1c3ccc(C(C)(C)C)cc3B3c4cc5sc6cc7c(cc6c5cc4N(c4ccccc4-c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5sc6cc7c(cc6c5c4N(c4ccccc4-c4ccccc4)c4cc(-c5c(C)cccc5C)cc1c43)C(C)(C)CCC7(C)C)C(C)(C)CCC2(C)C]

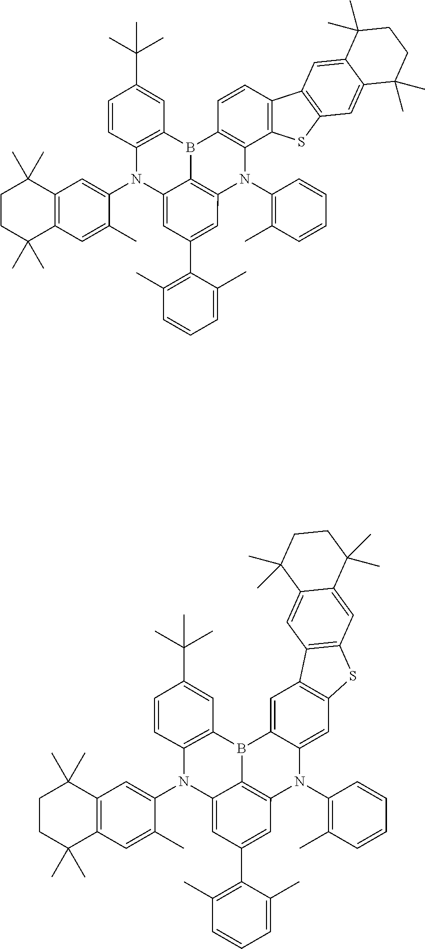 [SMILES: Cc1cc2c(cc1N1c3ccc(C(C)(C)C)cc3B3c4ccc5c(sc6cc7c(cc65)C(C)(C)CCC7(C)C)c4N(c4ccccc4C)c4cc(-c5c(C)cccc5C)cc1c43)C(C)(C)CCC2(C)C ; Cc1ccccc1N1c2cc3sc4cc5c(cc4c3cc2B2c3cc(C(C)(C)C)ccc3N(c3cc4c(cc3C)C(C)(C)CCC4(C)C)c3cc(-c4c(C)cccc4C)cc1c32)C(C)(C)CCC5(C)C]

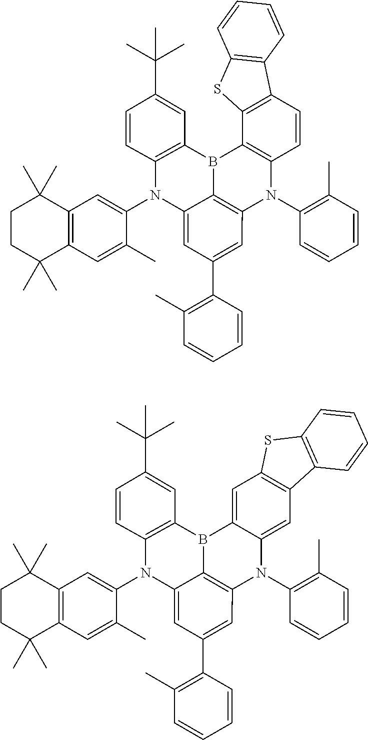 [SMILES: Cc1ccccc1-c1cc2c3c(c1)N(c1ccccc1C)c1ccc4c(sc5ccccc54)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)sc1ccccc14]

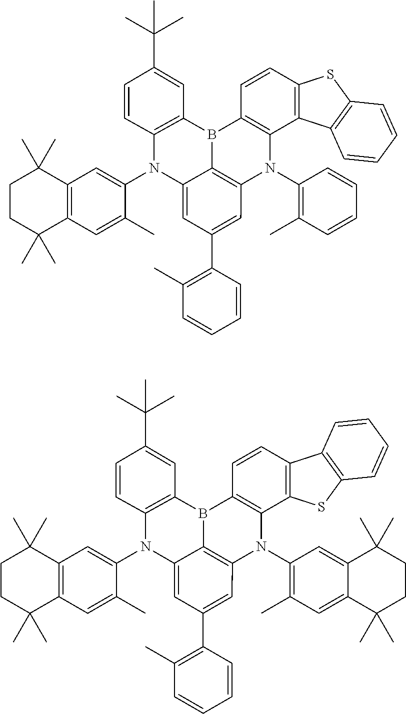 [SMILES: Cc1ccccc1-c1cc2c3c(c1)N(c1ccccc1C)c1c(ccc4sc5ccccc5c14)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1sc1ccccc14)B3c1cc(C(C)(C)C)ccc1N2c1cc2c(cc1C)C(C)(C)CCC2(C)C]

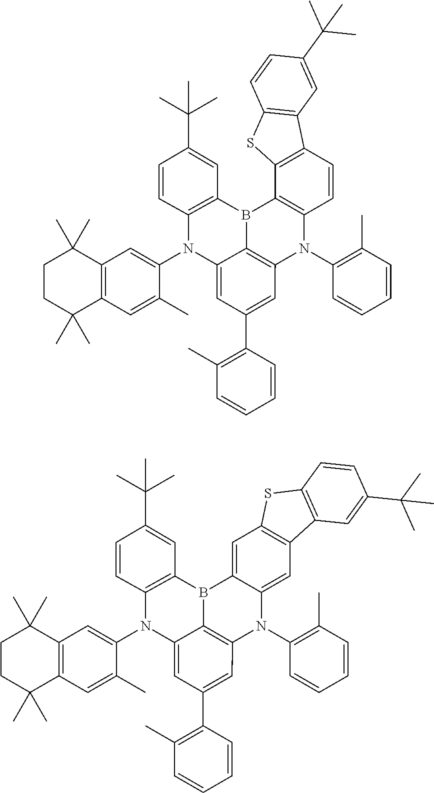 [SMILES: Cc1ccccc1-c1cc2c3c(c1)N(c1ccccc1C)c1ccc4c(sc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)sc1ccc(C(C)(C)C)cc14]

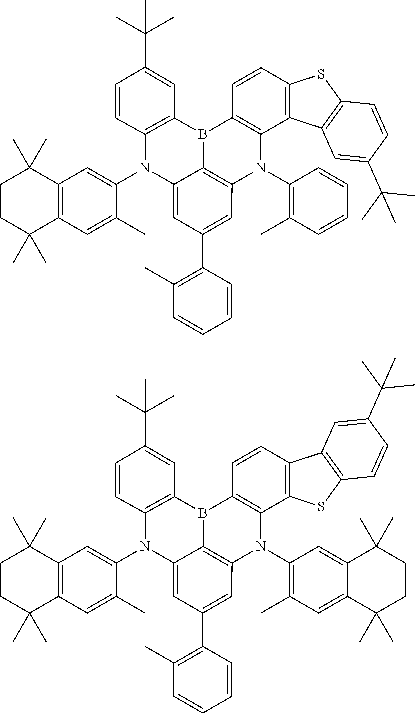 [SMILES: Cc1ccccc1-c1cc2c3c(c1)N(c1ccccc1C)c1c(ccc4sc5ccc(C(C)(C)C)cc5c14)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1sc1ccc(C(C)(C)C)cc14)B3c1cc(C(C)(C)C)ccc1N2c1cc2c(cc1C)C(C)(C)CCC2(C)C]

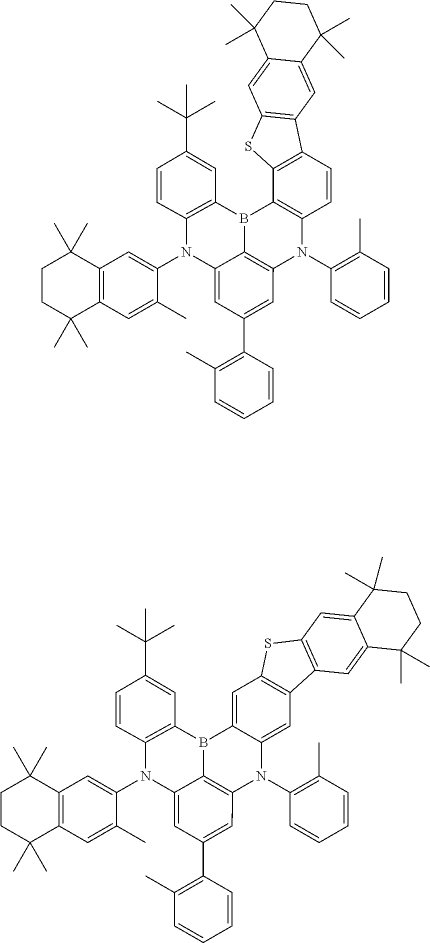 [SMILES: Cc1ccccc1-c1cc2c3c(c1)N(c1ccccc1C)c1ccc4c(sc5cc6c(cc54)C(C)(C)CCC6(C)C)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)sc1cc2c(cc14)C(C)(C)CCC2(C)C]

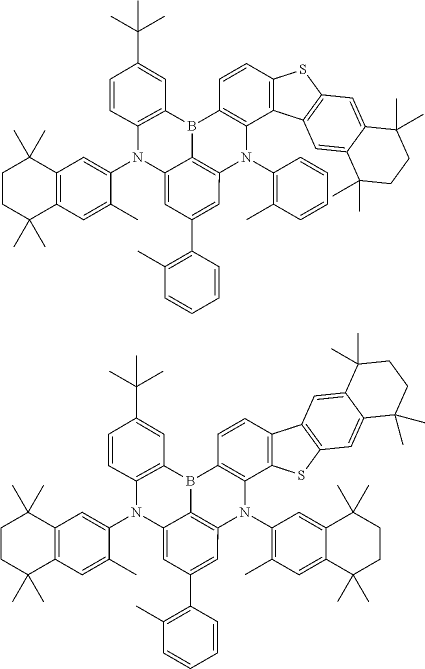 [SMILES: Cc1ccccc1-c1cc2c3c(c1)N(c1ccccc1C)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc(C(C)(C)C)ccc1N2c1cc2c(cc1C)C(C)(C)CCC2(C)C]

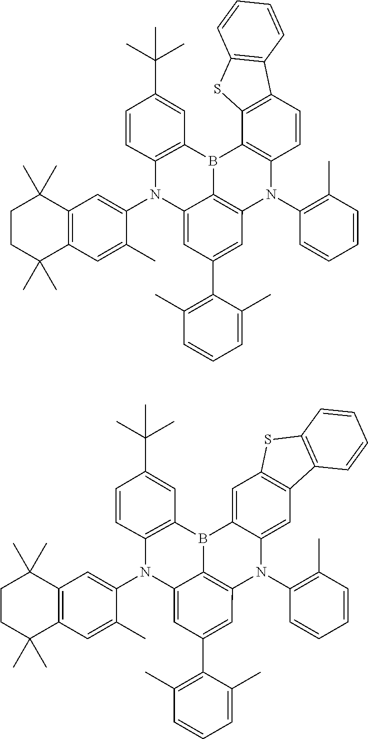 [SMILES: Cc1cc2c(cc1N1c3ccc(C(C)(C)C)cc3B3c4c1cc(-c1c(C)cccc1C)cc4N(c1ccccc1C)c1ccc4c(sc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)sc1ccccc13]

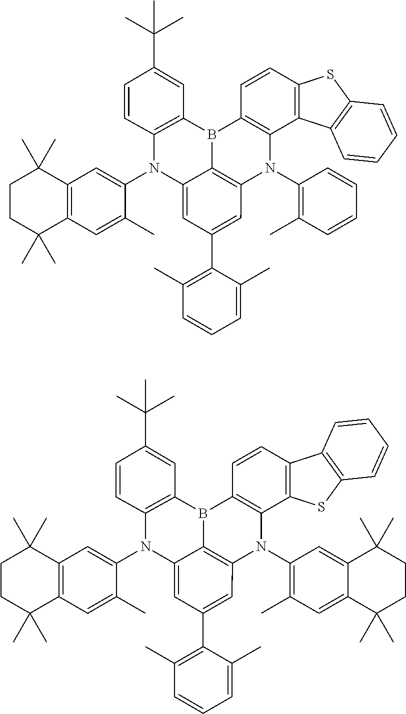 [SMILES: Cc1cc2c(cc1N1c3ccc(C(C)(C)C)cc3B3c4ccc5sc6ccccc6c5c4N(c4ccccc4C)c4cc(-c5c(C)cccc5C)cc1c43)C(C)(C)CCC2(C)C ; Cc1cc2c(cc1N1c3ccc(C(C)(C)C)cc3B3c4ccc5c(sc6ccccc65)c4N(c4cc5c(cc4C)C(C)(C)CCC5(C)C)c4cc(-c5c(C)cccc5C)cc1c43)C(C)(C)CCC2(C)C]

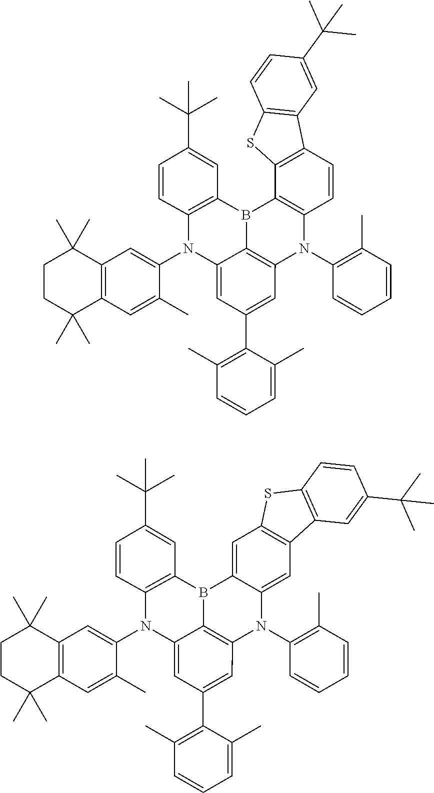 [SMILES: Cc1cc2c(cc1N1c3ccc(C(C)(C)C)cc3B3c4c1cc(-c1c(C)cccc1C)cc4N(c1ccccc1C)c1ccc4c(sc5ccc(C(C)(C)C)cc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)sc1ccc(C(C)(C)C)cc13]

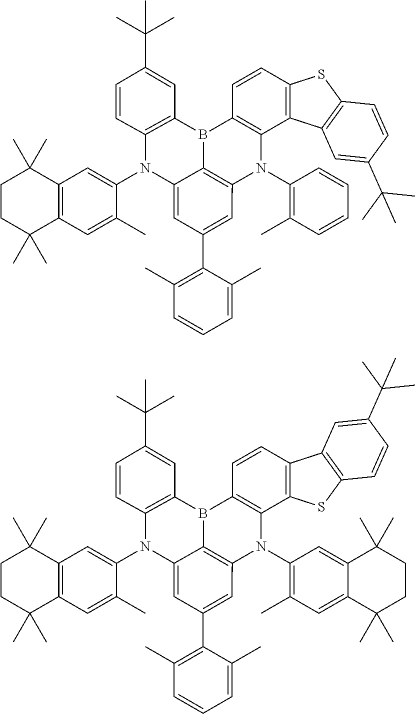 [SMILES: Cc1cc2c(cc1N1c3ccc(C(C)(C)C)cc3B3c4ccc5sc6ccc(C(C)(C)C)cc6c5c4N(c4ccccc4C)c4cc(-c5c(C)cccc5C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4cc5c(cc4C)C(C)(C)CCC5(C)C)c4cc(-c5c(C)cccc5C)cc1c43)C(C)(C)CCC2(C)C]

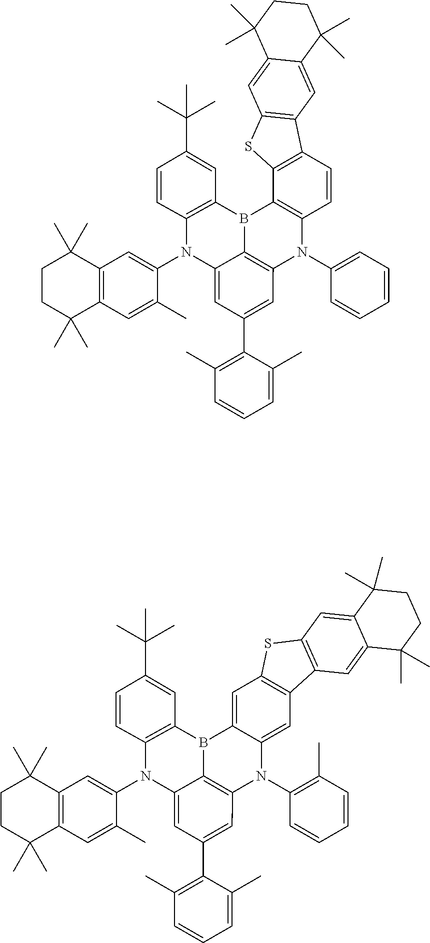 [SMILES: Cc1cc2c(cc1N1c3ccc(C(C)(C)C)cc3B3c4c(cc(-c5c(C)cccc5C)cc41)N(c1ccccc1)c1ccc4c(sc5cc6c(cc54)C(C)(C)CCC6(C)C)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)sc1cc2c(cc13)C(C)(C)CCC2(C)C]

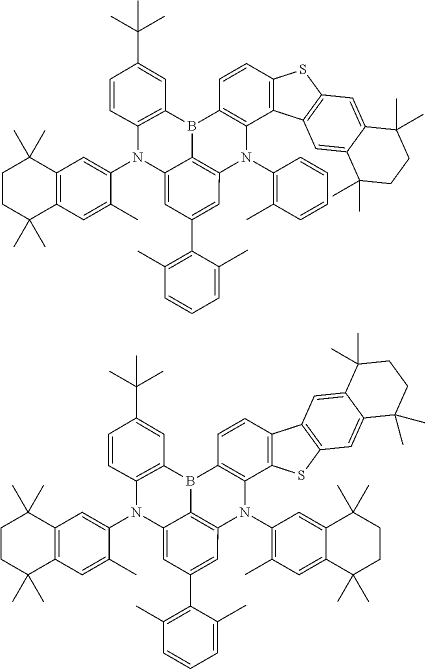 [SMILES: Cc1cc2c(cc1N1c3ccc(C(C)(C)C)cc3B3c4ccc5sc6cc7c(cc6c5c4N(c4ccccc4C)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4cc5c(cc4C)C(C)(C)CCC5(C)C)c4cc(-c5c(C)cccc5C)cc1c43)C(C)(C)CCC2(C)C]

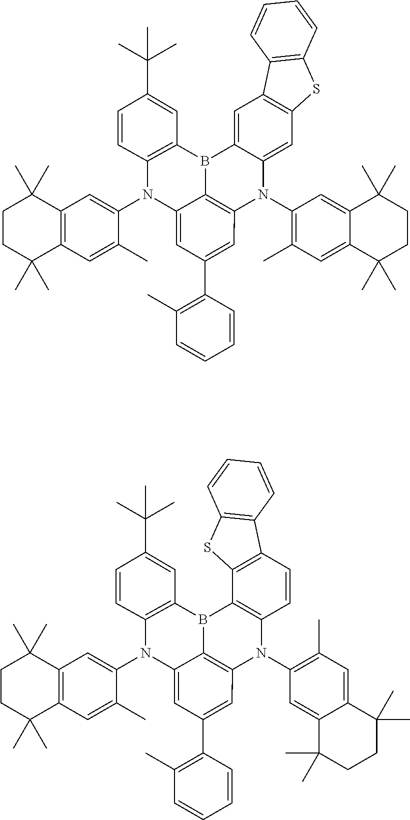 [SMILES: Cc1ccccc1-c1cc2c3c(c1)N(c1cc4c(cc1C)C(C)(C)CCC4(C)C)c1cc4sc5ccccc5c4cc1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1ccc4c(sc5ccccc54)c1B3c1cc(C(C)(C)C)ccc1N2c1cc2c(cc1C)C(C)(C)CCC2(C)C]

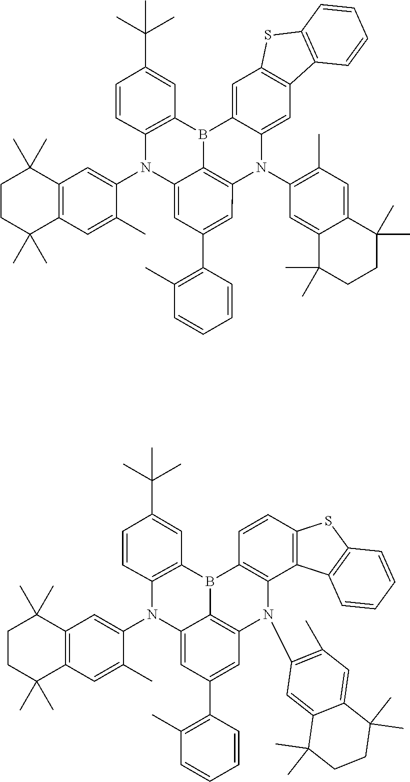 [SMILES: Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)sc1ccccc14 ; Cc1ccccc1-c1cc2c3c(c1)N(c1cc4c(cc1C)C(C)(C)CCC4(C)C)c1c(ccc4sc5ccccc5c14)B3c1cc(C(C)(C)C)ccc1N2c1cc2c(cc1C)C(C)(C)CCC2(C)C]

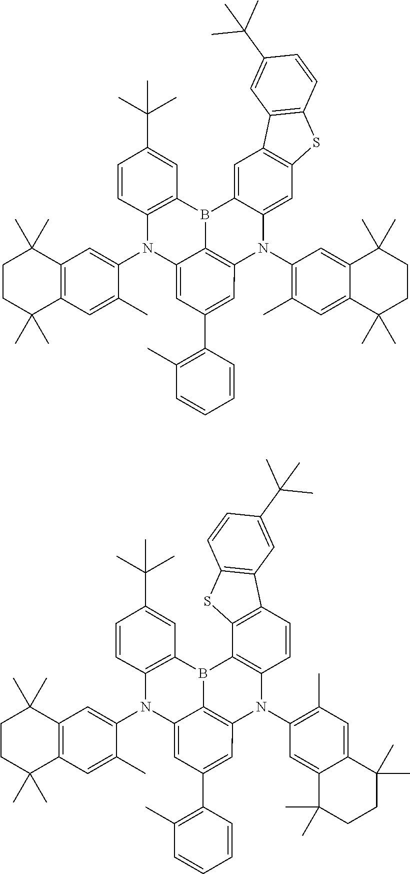 [SMILES: Cc1ccccc1-c1cc2c3c(c1)N(c1cc4c(cc1C)C(C)(C)CCC4(C)C)c1cc4sc5ccc(C(C)(C)C)cc5c4cc1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1ccc4c(sc5ccc(C(C)(C)C)cc54)c1B3c1cc(C(C)(C)C)ccc1N2c1cc2c(cc1C)C(C)(C)CCC2(C)C]

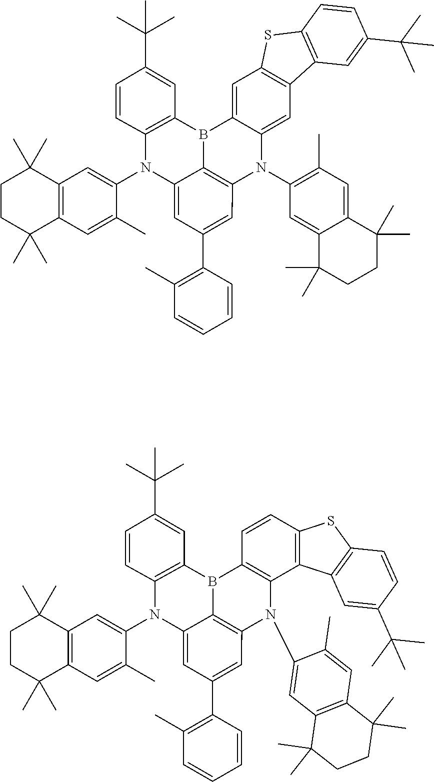 [SMILES: Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)sc1ccc(C(C)(C)C)cc14 ; Cc1ccccc1-c1cc2c3c(c1)N(c1cc4c(cc1C)C(C)(C)CCC4(C)C)c1c(ccc4sc5ccc(C(C)(C)C)cc5c14)B3c1cc(C(C)(C)C)ccc1N2c1cc2c(cc1C)C(C)(C)CCC2(C)C]

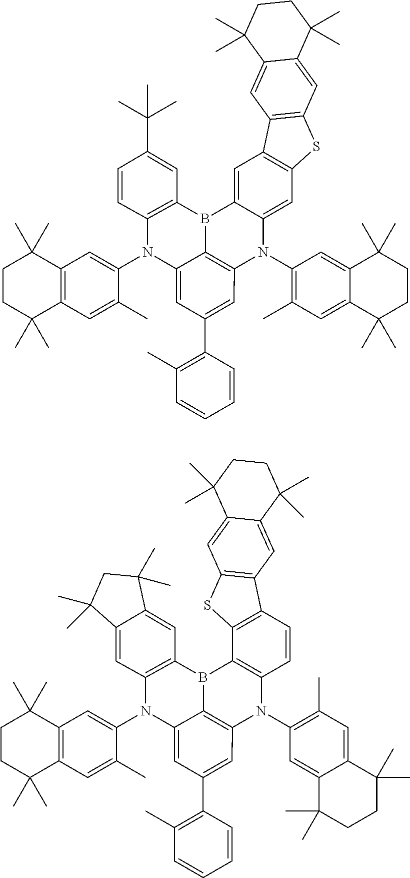 [SMILES: Cc1ccccc1-c1cc2c3c(c1)N(c1cc4c(cc1C)C(C)(C)CCC4(C)C)c1cc4sc5cc6c(cc5c4cc1B3c1cc(C(C)(C)C)ccc1N2c1cc2c(cc1C)C(C)(C)CCC2(C)C)C(C)(C)CCC6(C)C ; Cc1ccccc1-c1cc2c3c(c1)N(c1cc4c(cc1C)C(C)(C)CCC4(C)C)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C]

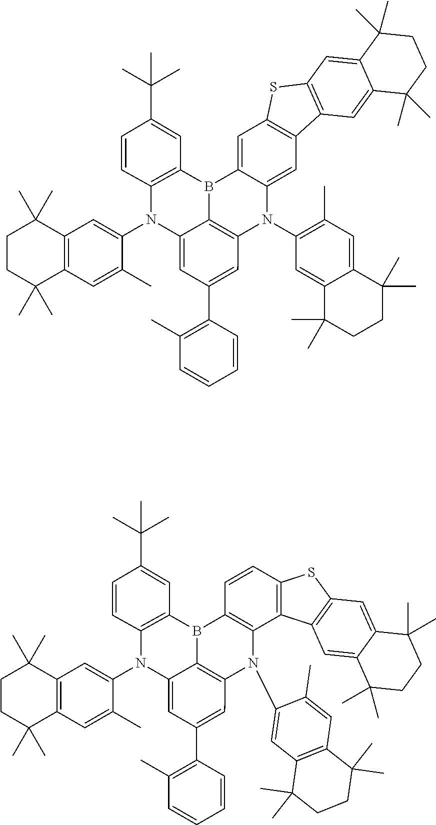 [SMILES: Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1ccccc1-c1cc2c3c(c1)N(c1cc4c(cc1C)C(C)(C)CCC4(C)C)c1c(ccc4sc5cc6c(cc5c14)C(C)(C)CCC6(C)C)B3c1cc(C(C)(C)C)ccc1N2c1cc2c(cc1C)C(C)(C)CCC2(C)C]

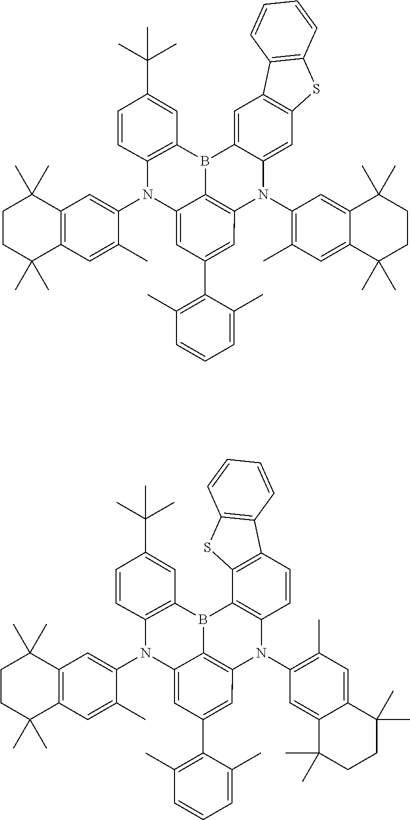 [SMILES: Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)sc1ccccc15)C(C)(C)CCC2(C)C ; Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(sc5ccccc54)c13)C(C)(C)CCC2(C)C]

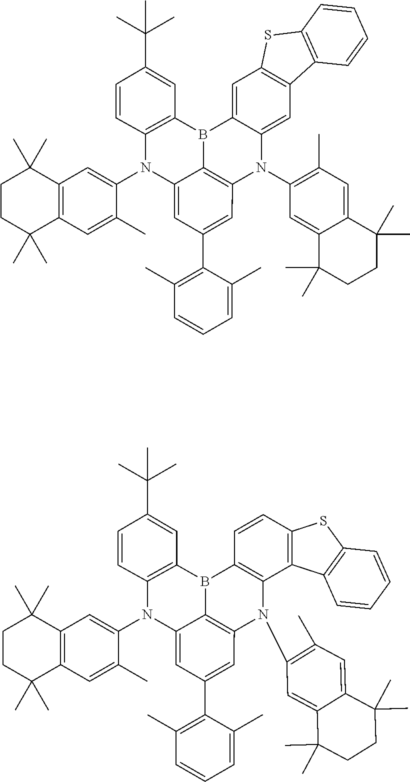 [SMILES: Cc1cc2c(cc1N1c3ccc(C(C)(C)C)cc3B3c4cc5sc6ccccc6c5cc4N(c4cc5c(cc4C)C(C)(C)CCC5(C)C)c4cc(-c5c(C)cccc5C)cc1c43)C(C)(C)CCC2(C)C ; Cc1cc2c(cc1N1c3ccc(C(C)(C)C)cc3B3c4ccc5sc6ccccc6c5c4N(c4cc5c(cc4C)C(C)(C)CCC5(C)C)c4cc(-c5c(C)cccc5C)cc1c43)C(C)(C)CCC2(C)C]

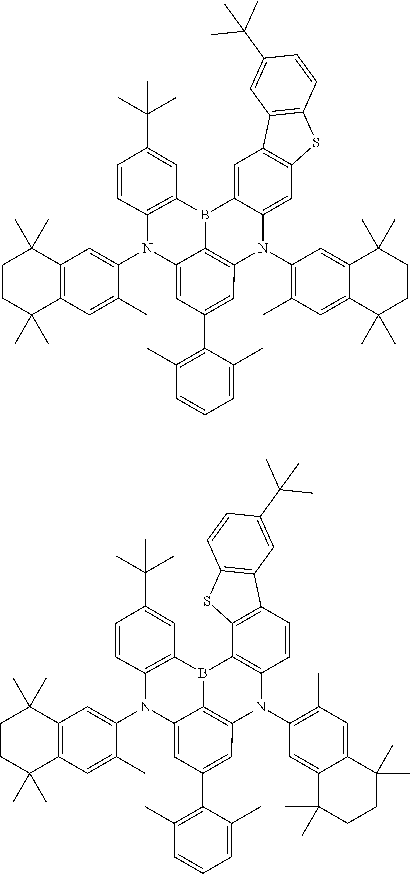 [SMILES: Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)sc1ccc(C(C)(C)C)cc15)C(C)(C)CCC2(C)C ; Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(sc5ccc(C(C)(C)C)cc54)c13)C(C)(C)CCC2(C)C]

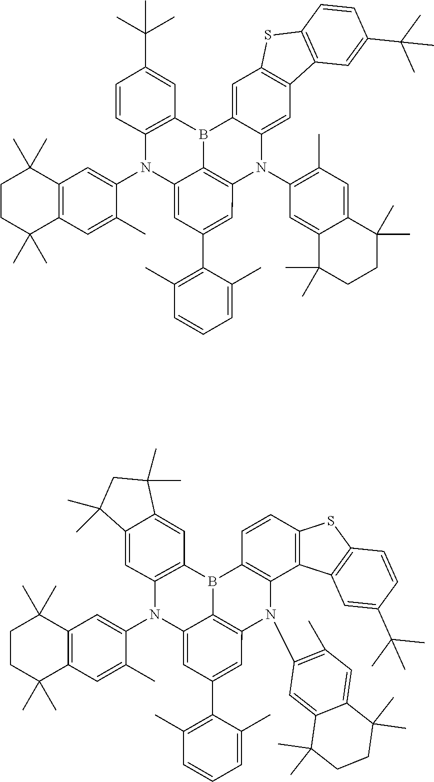 [SMILES: Cc1cc2c(cc1N1c3ccc(C(C)(C)C)cc3B3c4cc5sc6ccc(C(C)(C)C)cc6c5cc4N(c4cc5c(cc4C)C(C)(C)CCC5(C)C)c4cc(-c5c(C)cccc5C)cc1c43)C(C)(C)CCC2(C)C ; Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(-c6c(C)cccc6C)cc1c53)C(C)(C)CC4(C)C)C(C)(C)CCC2(C)C]

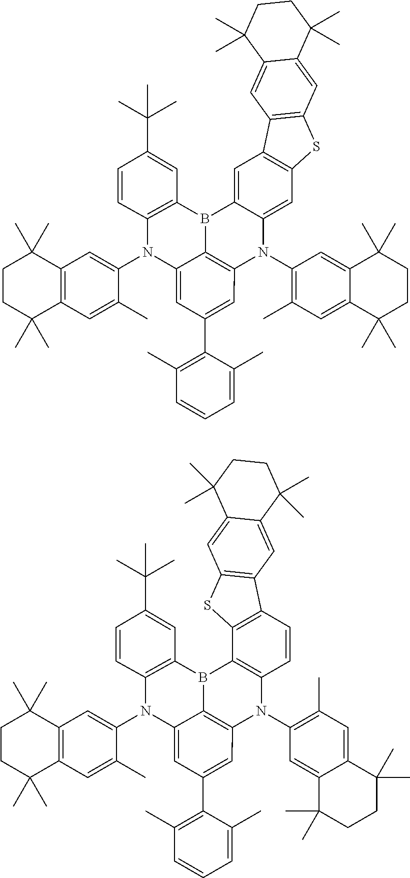 [SMILES: Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)sc1cc3c(cc15)C(C)(C)CCC3(C)C)C(C)(C)CCC2(C)C ; Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(sc5cc6c(cc54)C(C)(C)CCC6(C)C)c13)C(C)(C)CCC2(C)C]

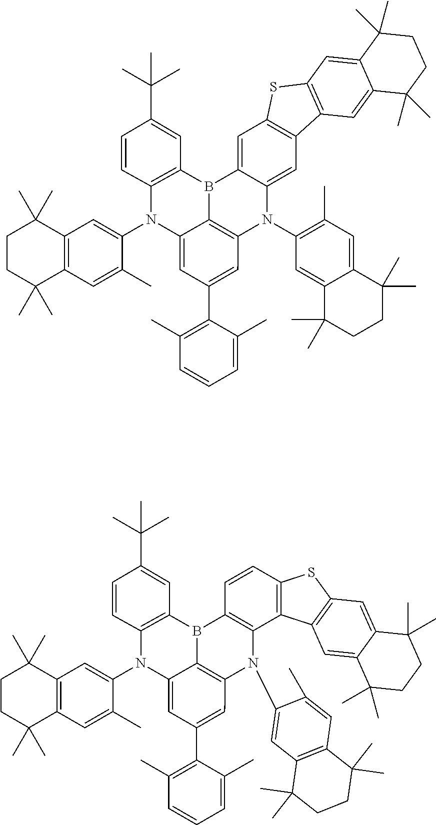 [SMILES: Cc1cc2c(cc1N1c3ccc(C(C)(C)C)cc3B3c4cc5sc6cc7c(cc6c5cc4N(c4cc5c(cc4C)C(C)(C)CCC5(C)C)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5sc6cc7c(cc6c5c4N(c4cc5c(cc4C)C(C)(C)CCC5(C)C)c4cc(-c5c(C)cccc5C)cc1c43)C(C)(C)CCC7(C)C)C(C)(C)CCC2(C)C]

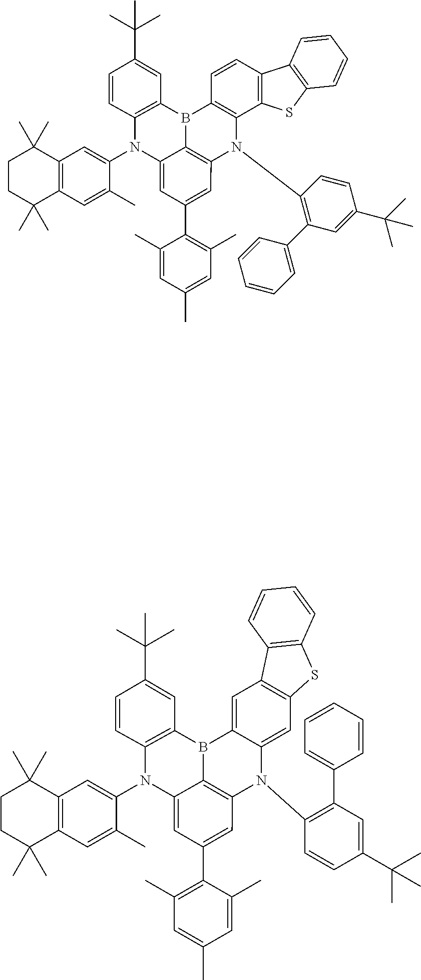 [SMILES: Cc1cc(C)c(-c2cc3c4c(c2)N(c2ccc(C(C)(C)C)cc2-c2ccccc2)c2c(ccc5c2sc2ccccc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc(C(C)(C)C)ccc2N3c2cc3c(cc2C)C(C)(C)CCC3(C)C)c(C)c1]

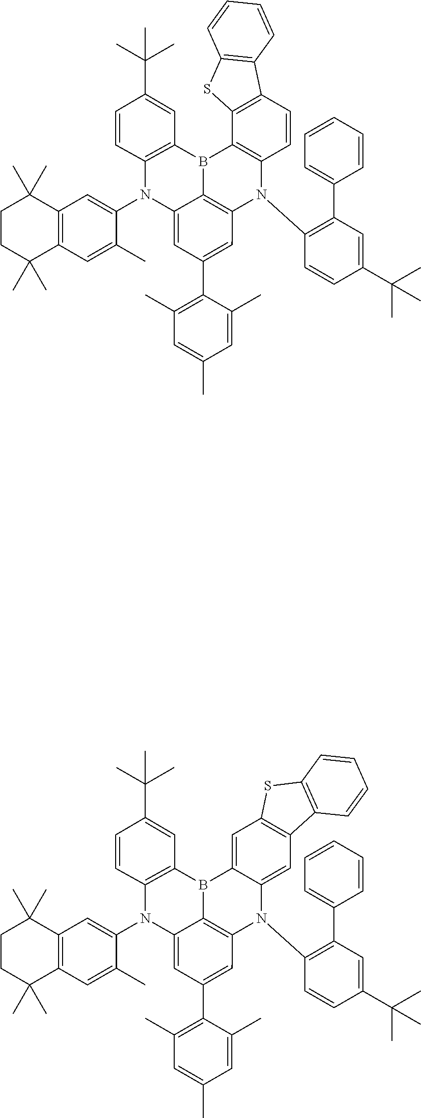 [SMILES: Cc1cc(C)c(-c2cc3c4c(c2)N(c2ccc(C(C)(C)C)cc2-c2ccccc2)c2ccc5c(sc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)sc2ccccc25)c(C)c1]

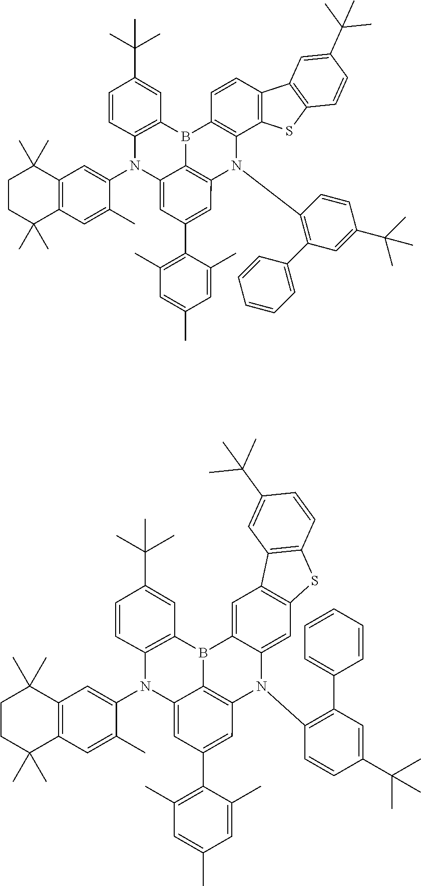 [SMILES: Cc1cc(C)c(-c2cc3c4c(c2)N(c2ccc(C(C)(C)C)cc2-c2ccccc2)c2c(ccc5c2sc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc(C(C)(C)C)ccc2N3c2cc3c(cc2C)C(C)(C)CCC3(C)C)c(C)c1]

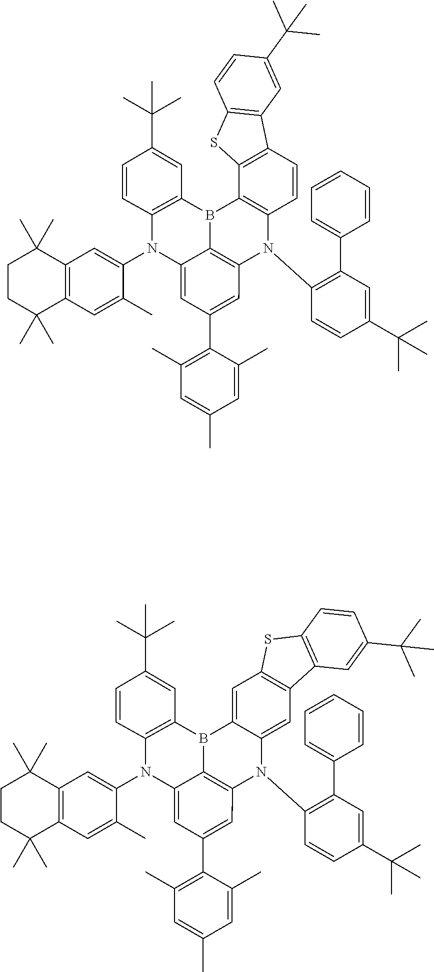 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)sc2ccc(C(C)(C)C)cc25)c(C)c1]

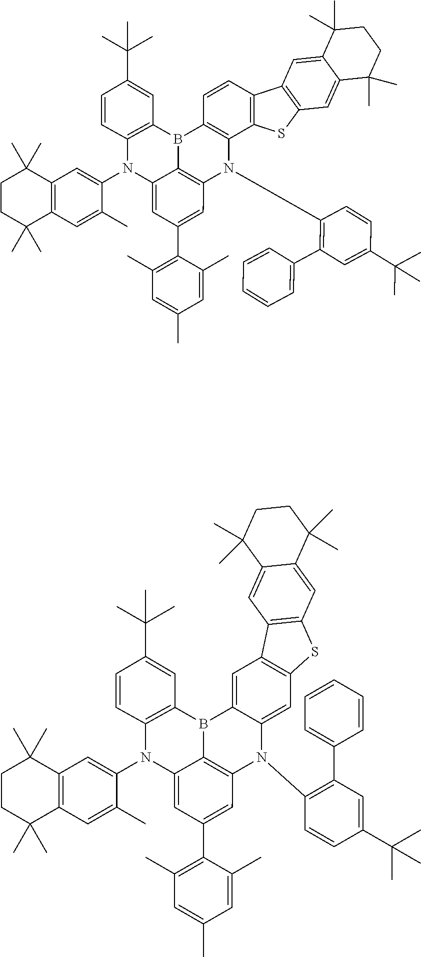 [SMILES: Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5sc6cc7c(cc6c5cc2B4c2cc(C(C)(C)C)ccc2N3c2cc3c(cc2C)C(C)(C)CCC3(C)C)C(C)(C)CCC7(C)C)c(C)c1]

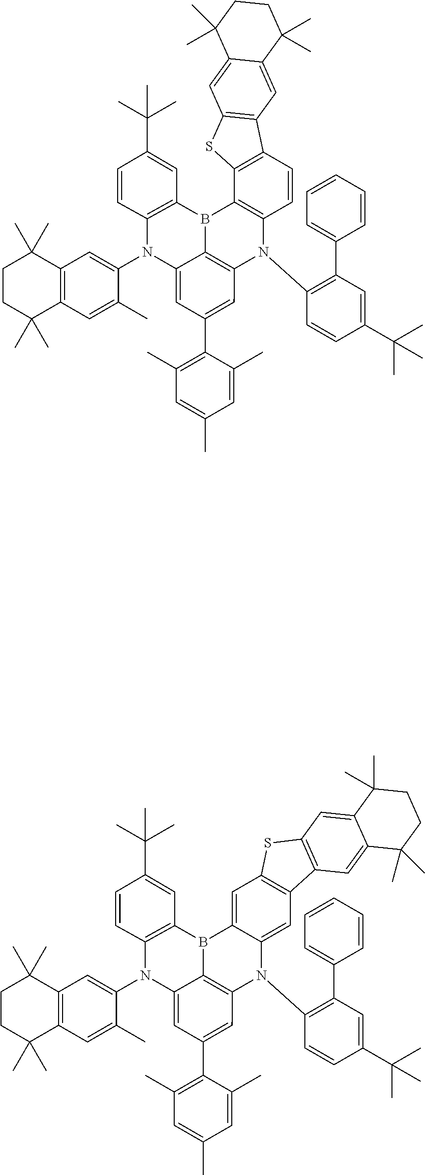 [SMILES: Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)sc2cc3c(cc25)C(C)(C)CCC3(C)C)c(C)c1]

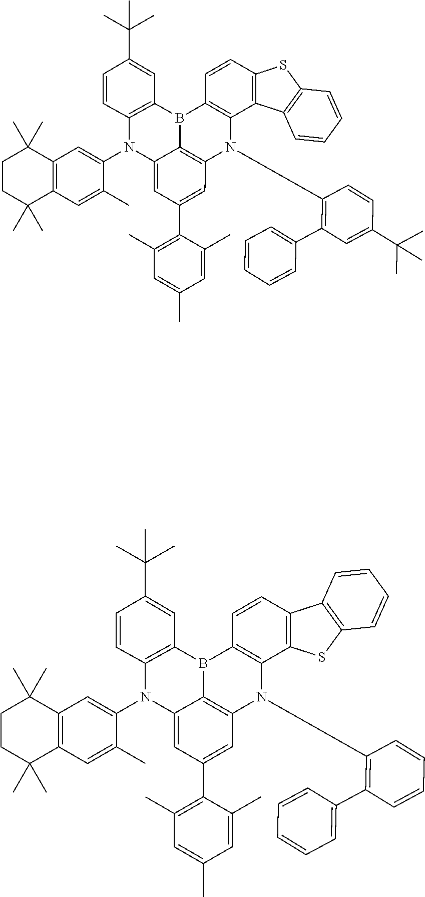 [SMILES: Cc1cc(C)c(-c2cc3c4c(c2)N(c2ccc(C(C)(C)C)cc2-c2ccccc2)c2c(ccc5sc6ccccc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2sc2ccccc25)B4c2cc(C(C)(C)C)ccc2N3c2cc3c(cc2C)C(C)(C)CCC3(C)C)c(C)c1]

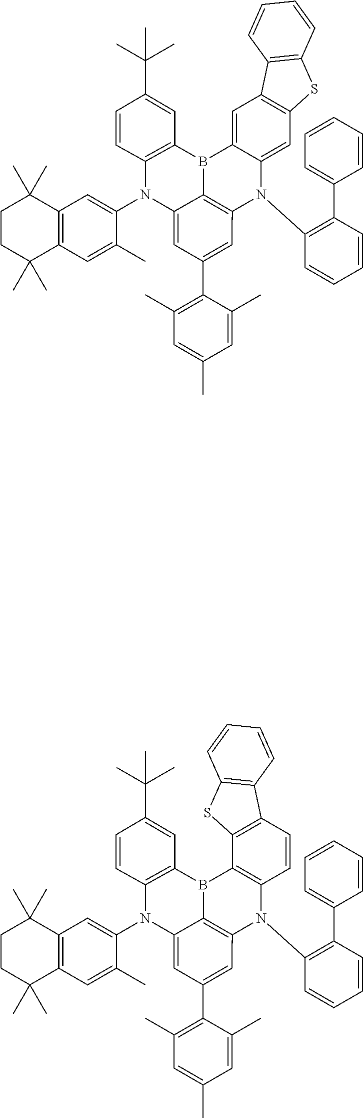 [SMILES: Cc1cc(C)c(-c2cc3c4c(c2)N(c2ccccc2-c2ccccc2)c2cc5sc6ccccc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2ccc5c(sc6ccccc65)c2B4c2cc(C(C)(C)C)ccc2N3c2cc3c(cc2C)C(C)(C)CCC3(C)C)c(C)c1]

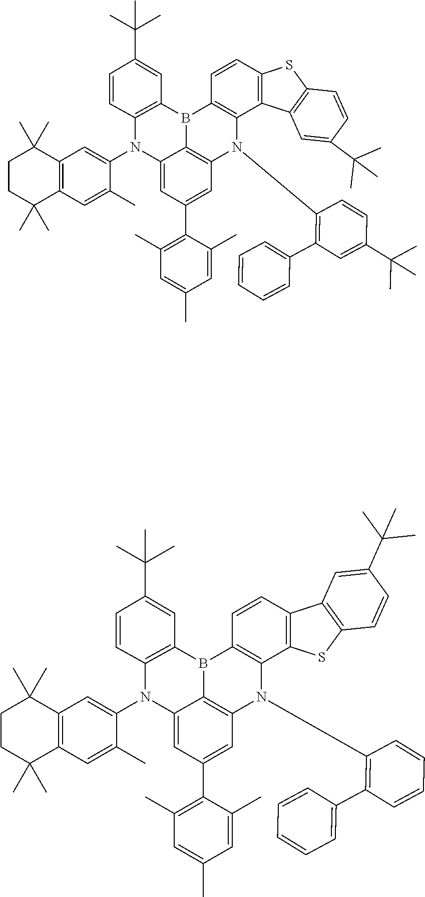 [SMILES: Cc1cc(C)c(-c2cc3c4c(c2)N(c2ccc(C(C)(C)C)cc2-c2ccccc2)c2c(ccc5sc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc(C(C)(C)C)ccc2N3c2cc3c(cc2C)C(C)(C)CCC3(C)C)c(C)c1]

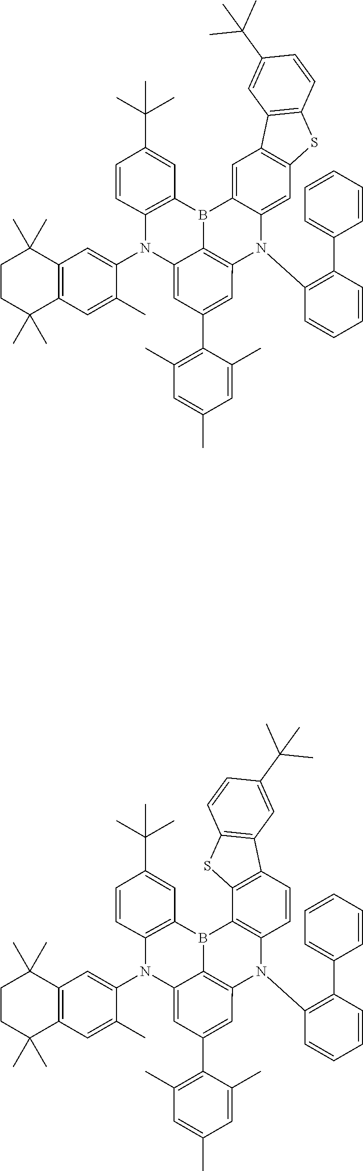 [SMILES: Cc1cc(C)c(-c2cc3c4c(c2)N(c2ccccc2-c2ccccc2)c2cc5sc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc(C(C)(C)C)ccc2N3c2cc3c(cc2C)C(C)(C)CCC3(C)C)c(C)c1]

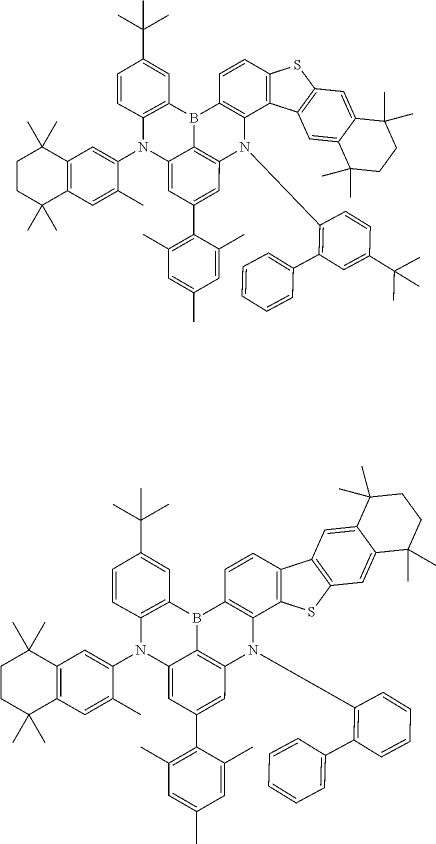 [SMILES: Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2sc2cc6c(cc25)C(C)(C)CCC6(C)C)B4c2cc(C(C)(C)C)ccc2N3c2cc3c(cc2C)C(C)(C)CCC3(C)C)c(C)c1]

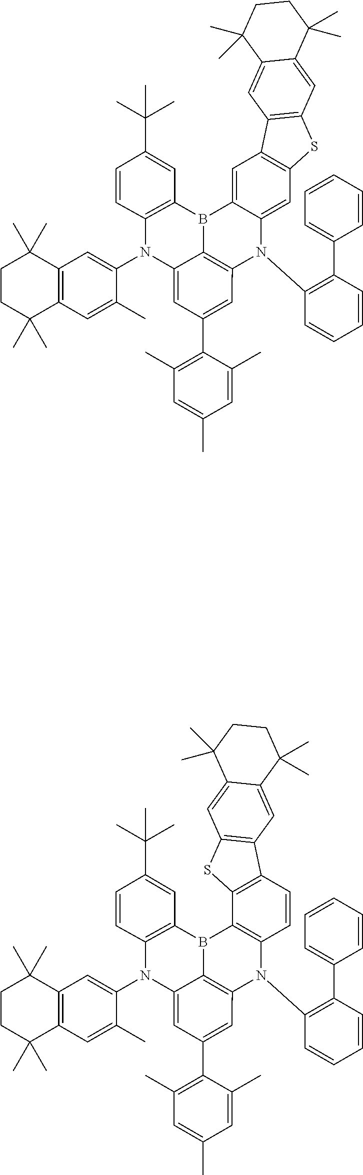 [SMILES: Cc1cc(C)c(-c2cc3c4c(c2)N(c2ccccc2-c2ccccc2)c2cc5sc6cc7c(cc6c5cc2B4c2cc(C(C)(C)C)ccc2N3c2cc3c(cc2C)C(C)(C)CCC3(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc(C(C)(C)C)ccc2N3c2cc3c(cc2C)C(C)(C)CCC3(C)C)c(C)c1]

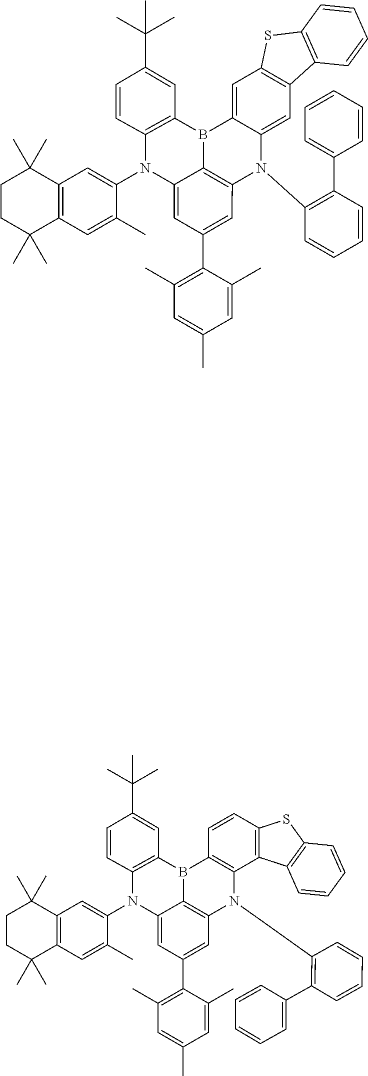 [SMILES: Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc(C(C)(C)C)ccc2N3c2cc3c(cc2C)C(C)(C)CCC3(C)C)c(C)c1]

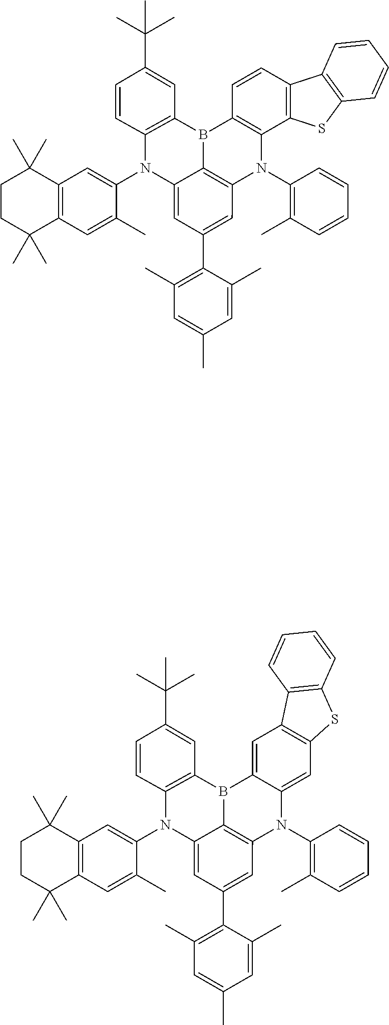 [SMILES: Cc1cc(C)c(-c2cc3c4c(c2)N(c2ccccc2C)c2c(ccc5c2sc2ccccc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5sc6ccccc6c5cc2B4c2cc(C(C)(C)C)ccc2N3c2cc3c(cc2C)C(C)(C)CCC3(C)C)c(C)c1]

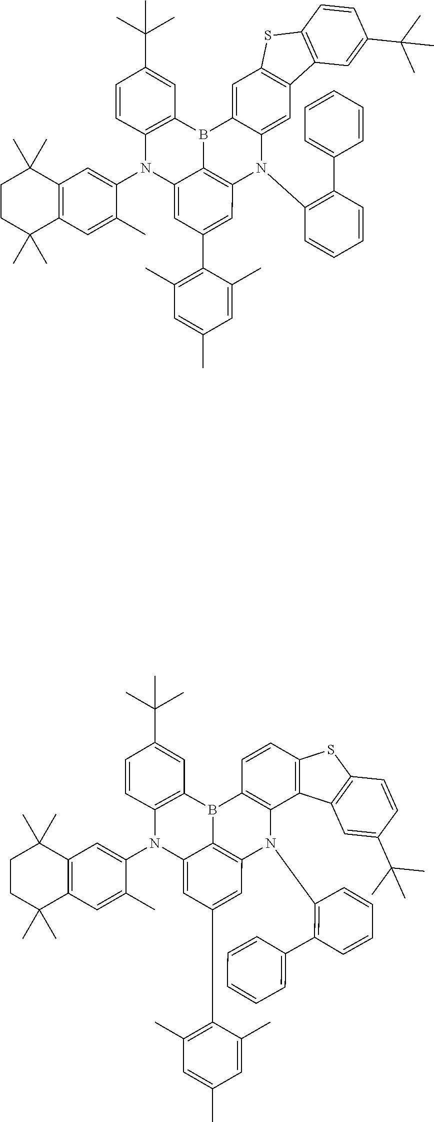 [SMILES: Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)sc2ccc(C(C)(C)C)cc25)c(C)c1 ; Cc1cc(C)c(-c2cc3c4c(c2)N(c2ccccc2-c2ccccc2)c2c(ccc5sc6ccc(C(C)(C)C)cc6c25)B4c2cc(C(C)(C)C)ccc2N3c2cc3c(cc2C)C(C)(C)CCC3(C)C)c(C)c1]

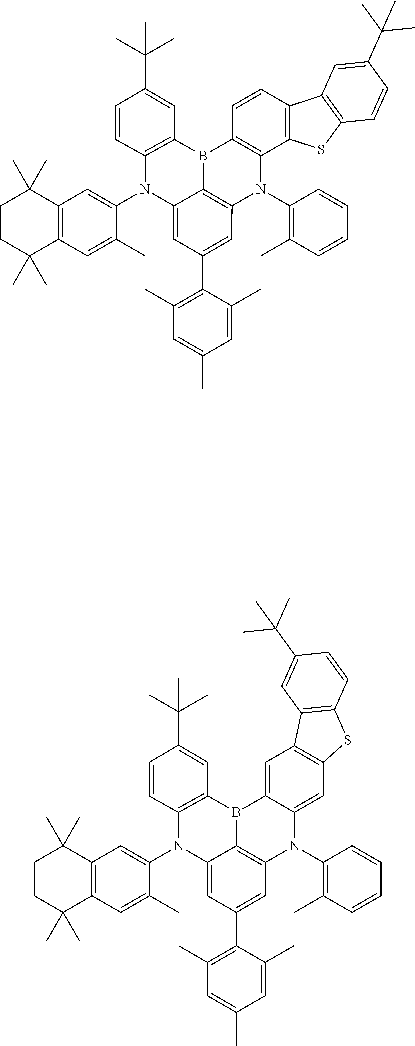 [SMILES: Cc1cc(C)c(-c2cc3c4c(c2)N(c2ccccc2C)c2c(ccc5c2sc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5sc6ccc(C(C)(C)C)cc6c5cc2B4c2cc(C(C)(C)C)ccc2N3c2cc3c(cc2C)C(C)(C)CCC3(C)C)c(C)c1]

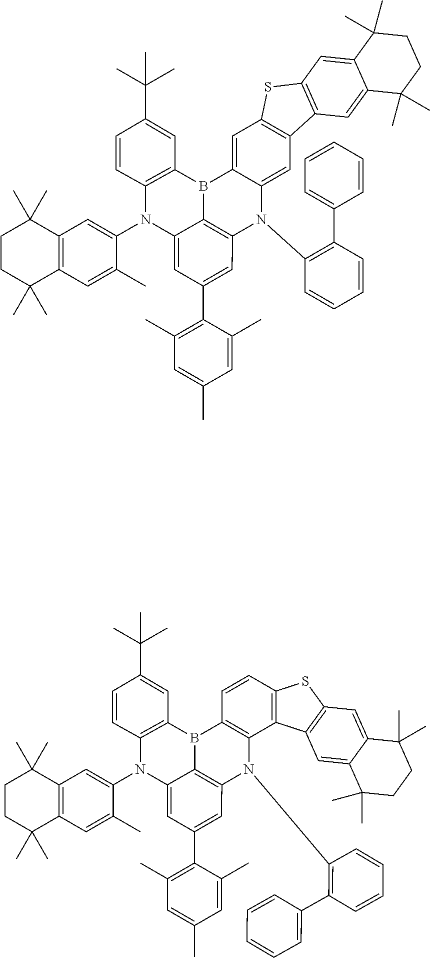 [SMILES: Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)sc2cc3c(cc25)C(C)(C)CCC3(C)C)c(C)c1 ; Cc1cc(C)c(-c2cc3c4c(c2)N(c2ccccc2-c2ccccc2)c2c(ccc5sc6cc7c(cc6c25)C(C)(C)CCC7(C)C)B4c2cc(C(C)(C)C)ccc2N3c2cc3c(cc2C)C(C)(C)CCC3(C)C)c(C)c1]

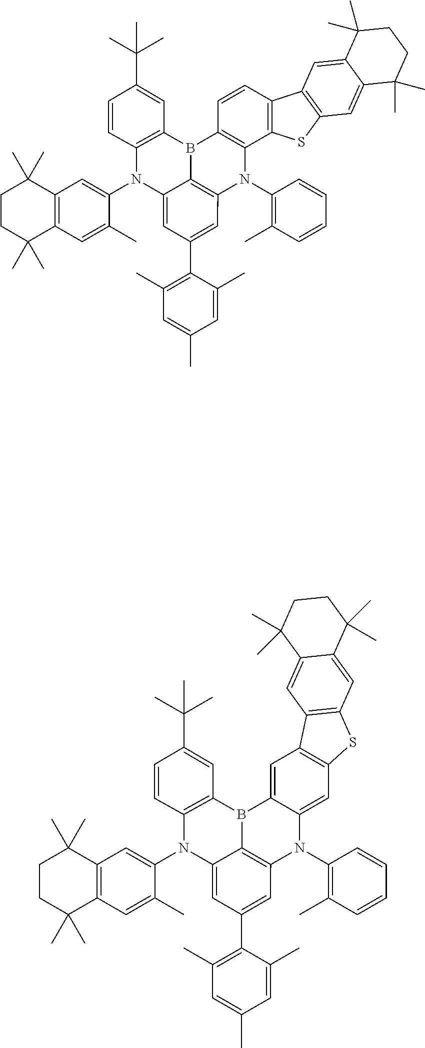 [SMILES: Cc1cc(C)c(-c2cc3c4c(c2)N(c2ccccc2C)c2c(ccc5c2sc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5sc6cc7c(cc6c5cc2B4c2cc(C(C)(C)C)ccc2N3c2cc3c(cc2C)C(C)(C)CCC3(C)C)C(C)(C)CCC7(C)C)c(C)c1]

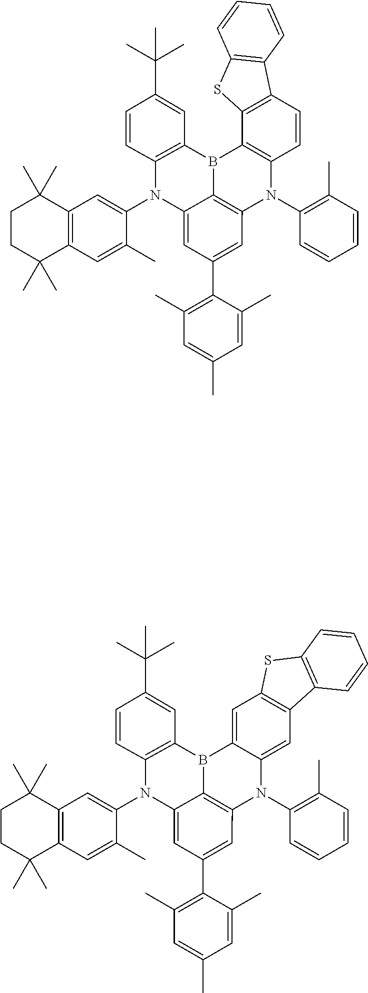 [SMILES: Cc1cc(C)c(-c2cc3c4c(c2)N(c2ccccc2C)c2ccc5c(sc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)sc2ccccc25)c(C)c1]

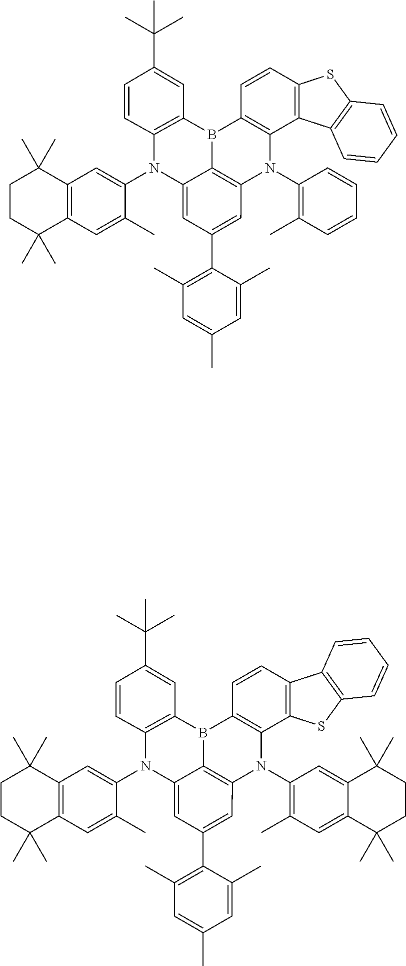 [SMILES: Cc1cc(C)c(-c2cc3c4c(c2)N(c2ccccc2C)c2c(ccc5sc6ccccc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2sc2ccccc25)B4c2cc(C(C)(C)C)ccc2N3c2cc3c(cc2C)C(C)(C)CCC3(C)C)c(C)c1]

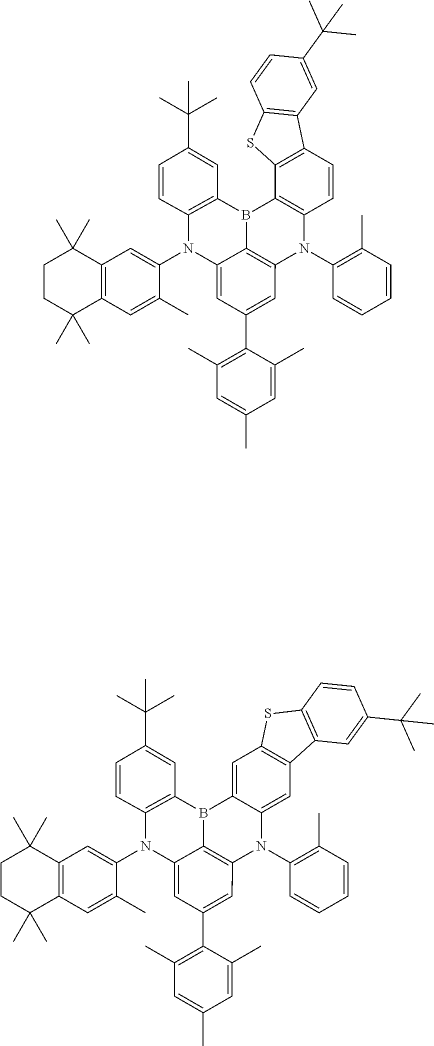 [SMILES: Cc1cc(C)c(-c2cc3c4c(c2)N(c2ccccc2C)c2ccc5c(sc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)sc2ccc(C(C)(C)C)cc25)c(C)c1]

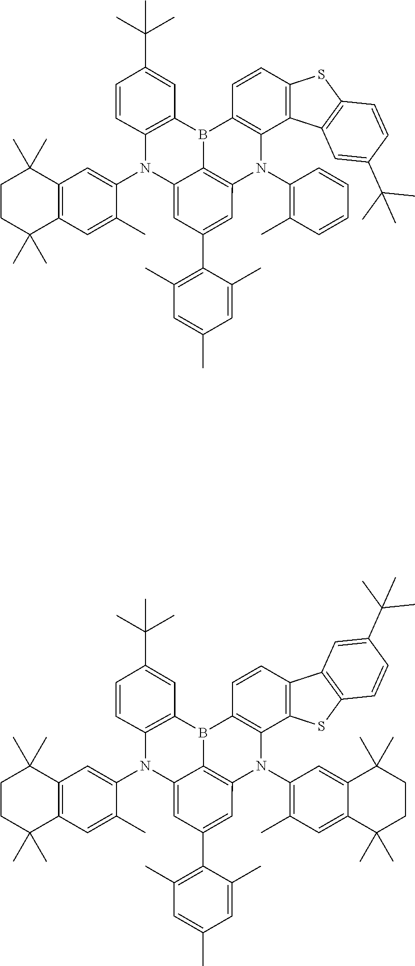 [SMILES: Cc1cc(C)c(-c2cc3c4c(c2)N(c2ccccc2C)c2c(ccc5sc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc(C(C)(C)C)ccc2N3c2cc3c(cc2C)C(C)(C)CCC3(C)C)c(C)c1]

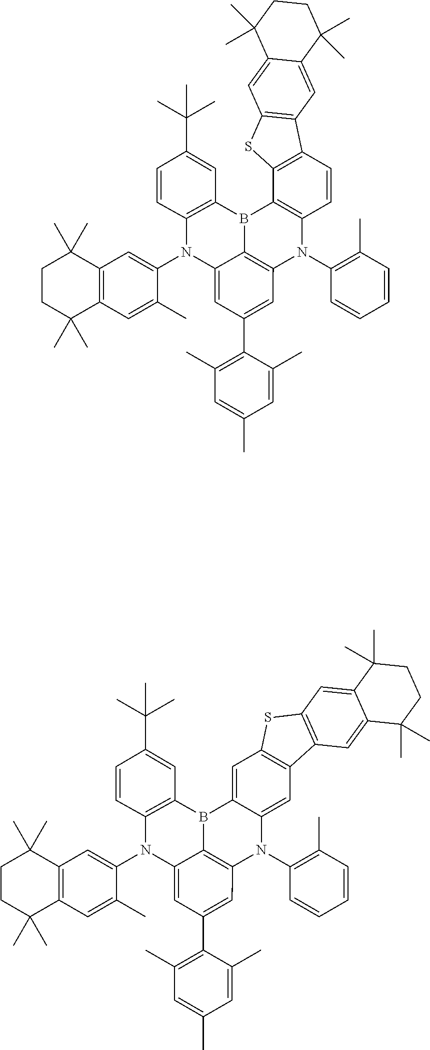 [SMILES: Cc1cc(C)c(-c2cc3c4c(c2)N(c2ccccc2C)c2ccc5c(sc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)sc2cc3c(cc25)C(C)(C)CCC3(C)C)c(C)c1]

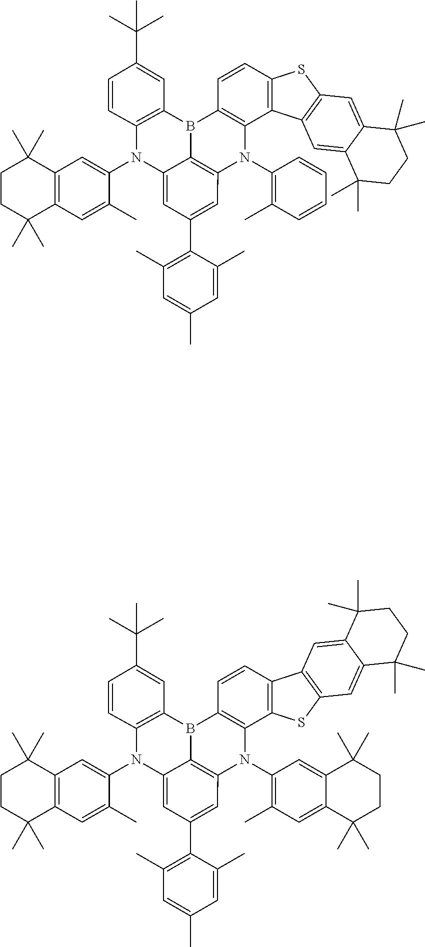 [SMILES: Cc1cc(C)c(-c2cc3c4c(c2)N(c2ccccc2C)c2c(ccc5sc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc(C(C)(C)C)ccc2N3c2cc3c(cc2C)C(C)(C)CCC3(C)C)c(C)c1]

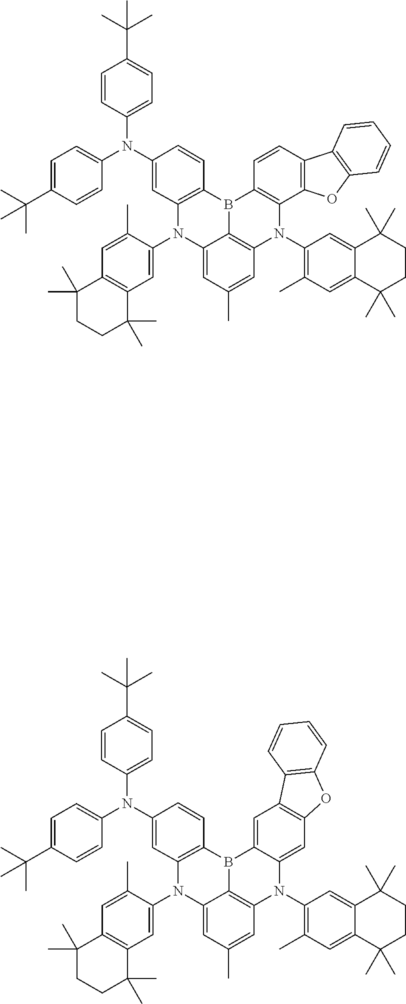 [SMILES: Cc1cc2c3c(c1)N(c1cc4c(cc1C)C(C)(C)CCC4(C)C)c1c(ccc4c1oc1ccccc14)B3c1ccc(N(c3ccc(C(C)(C)C)cc3)c3ccc(C(C)(C)C)cc3)cc1N2c1cc2c(cc1C)C(C)(C)CCC2(C)C ; Cc1cc2c3c(c1)N(c1cc4c(cc1C)C(C)(C)CCC4(C)C)c1cc4oc5ccccc5c4cc1B3c1ccc(N(c3ccc(C(C)(C)C)cc3)c3ccc(C(C)(C)C)cc3)cc1N2c1cc2c(cc1C)C(C)(C)CCC2(C)C]

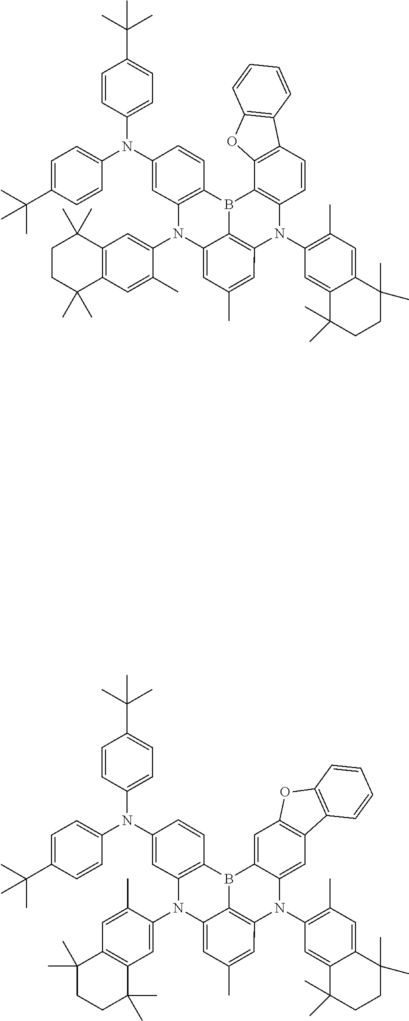

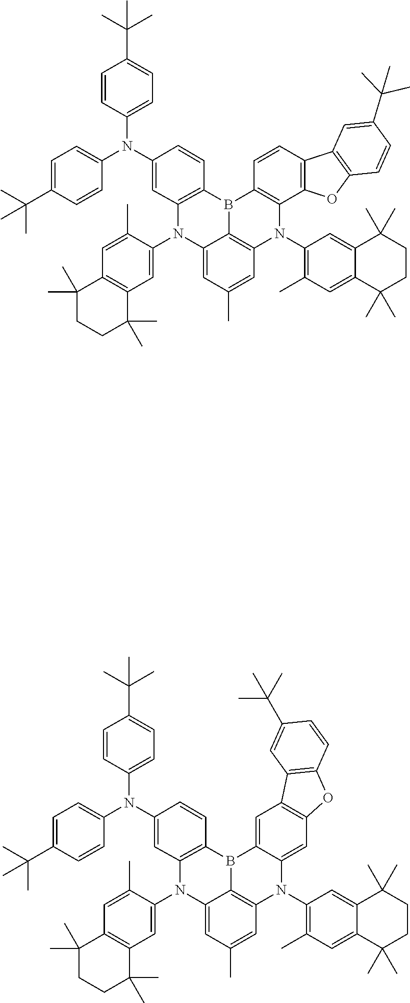

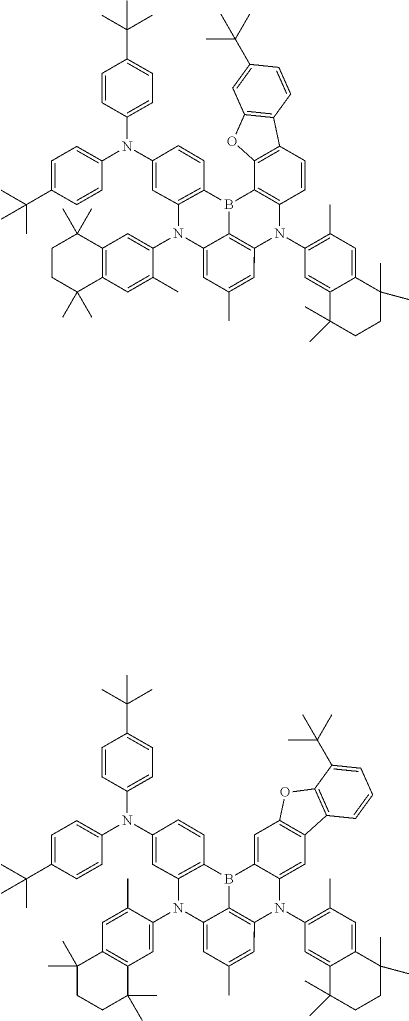

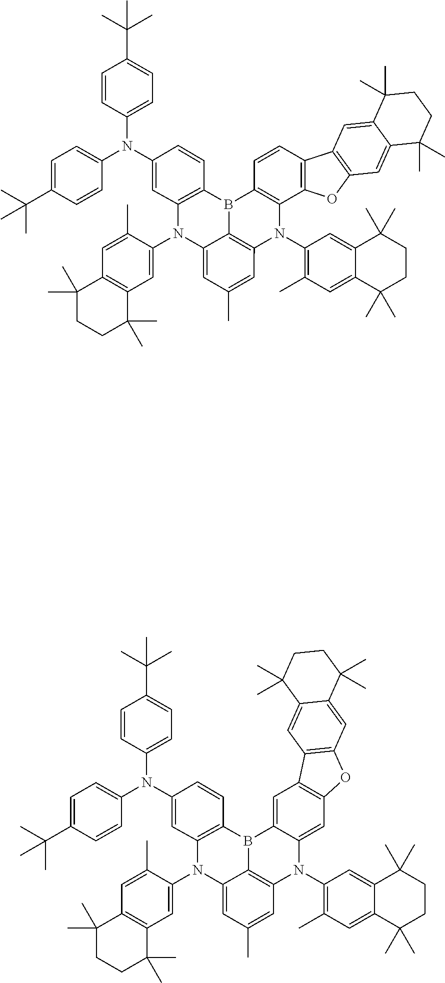

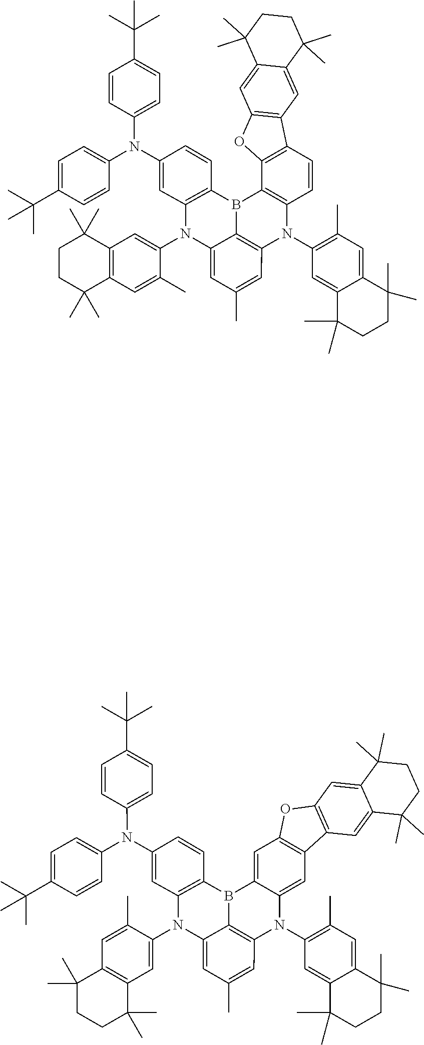

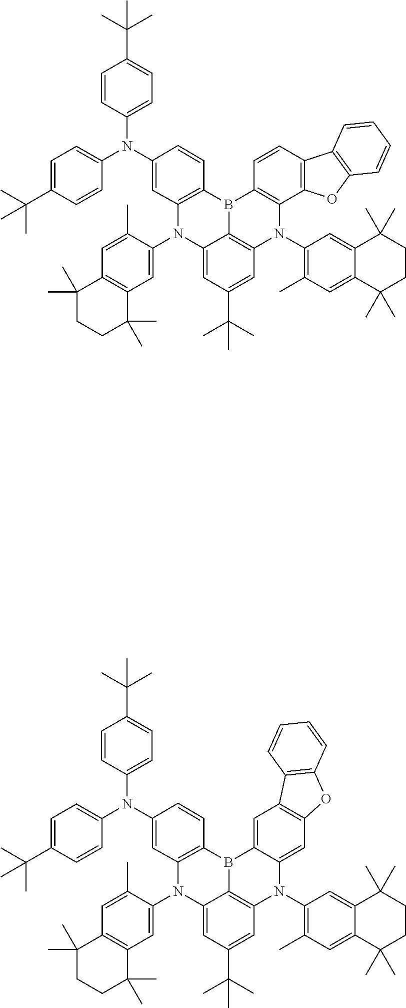 [SMILES: Cc1cc2c(cc1N1c3cc(N(c4ccc(C(C)(C)C)cc4)c4ccc(C(C)(C)C)cc4)ccc3B3c4ccc5c(oc6ccccc65)c4N(c4cc5c(cc4C)C(C)(C)CCC5(C)C)c4cc(C(C)(C)C)cc1c43)C(C)(C)CCC2(C)C ; Cc1cc2c(cc1N1c3cc(N(c4ccc(C(C)(C)C)cc4)c4ccc(C(C)(C)C)cc4)ccc3B3c4cc5c(cc4N(c4cc6c(cc4C)C(C)(C)CCC6(C)C)c4cc(C(C)(C)C)cc1c43)oc1ccccc15)C(C)(C)CCC2(C)C]

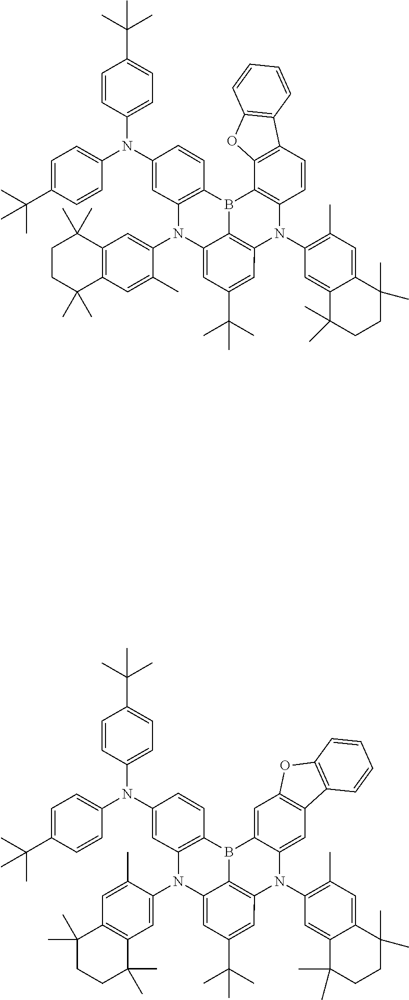

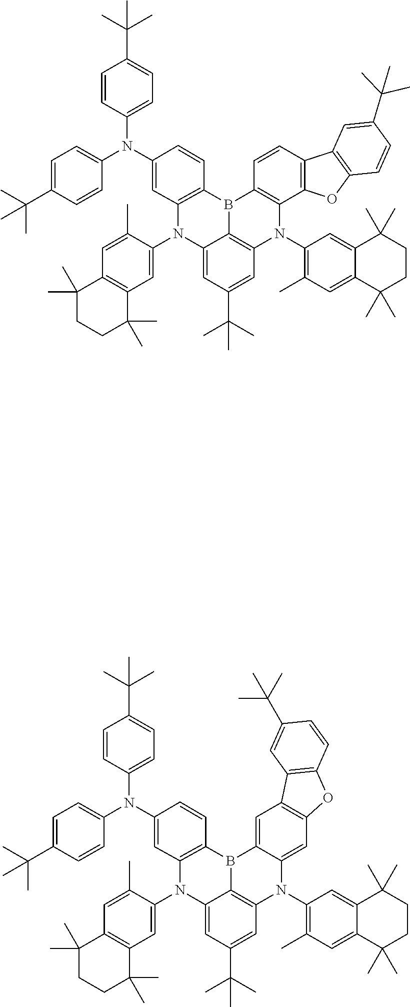

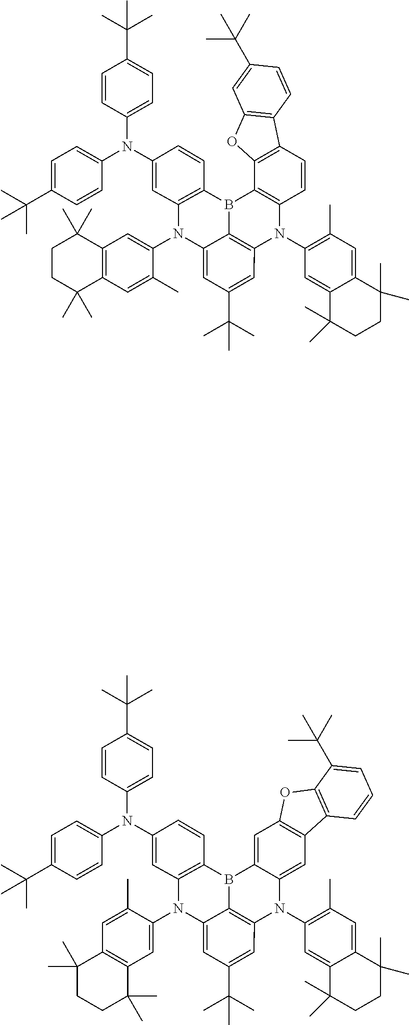

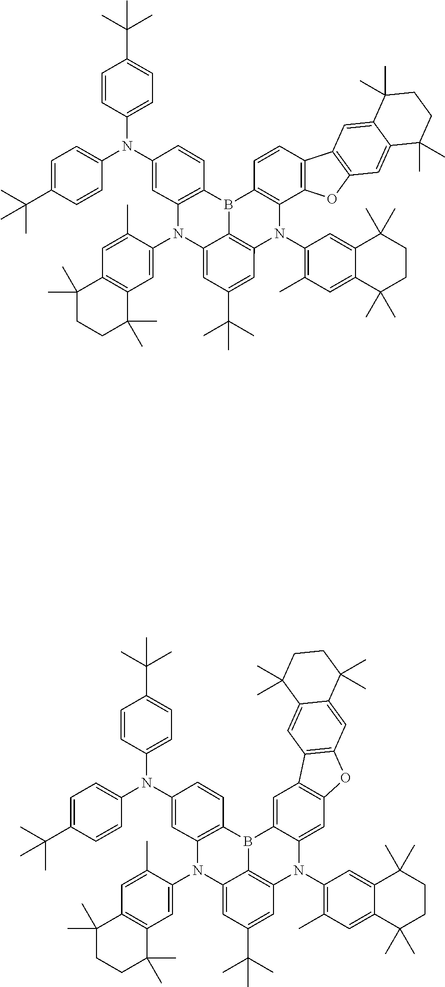

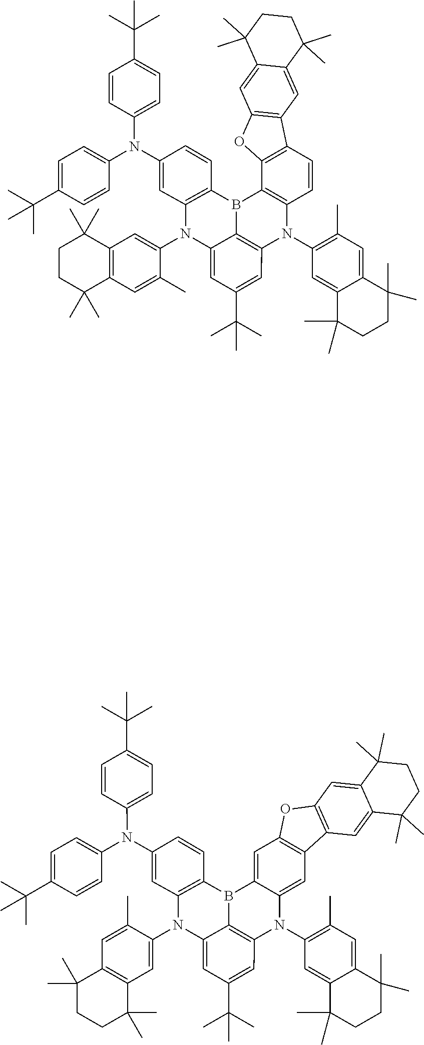

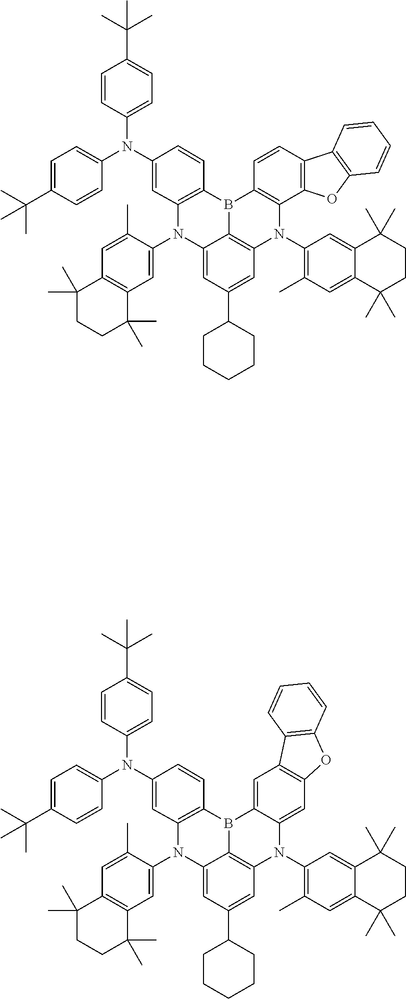 [SMILES: Cc1cc2c(cc1N1c3cc(N(c4ccc(C(C)(C)C)cc4)c4ccc(C(C)(C)C)cc4)ccc3B3c4ccc5c(oc6ccccc65)c4N(c4cc5c(cc4C)C(C)(C)CCC5(C)C)c4cc(C5CCCCC5)cc1c43)C(C)(C)CCC2(C)C ; Cc1cc2c(cc1N1c3cc(N(c4ccc(C(C)(C)C)cc4)c4ccc(C(C)(C)C)cc4)ccc3B3c4cc5c(cc4N(c4cc6c(cc4C)C(C)(C)CCC6(C)C)c4cc(C6CCCCC6)cc1c43)oc1ccccc15)C(C)(C)CCC2(C)C]

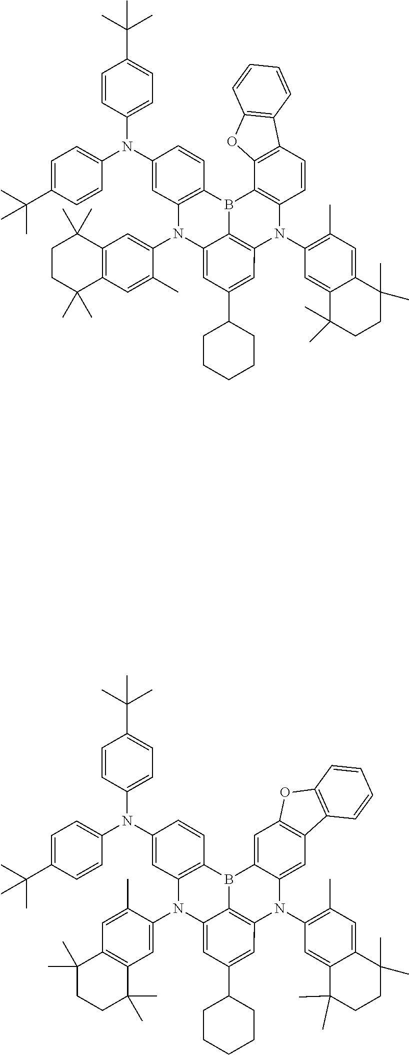

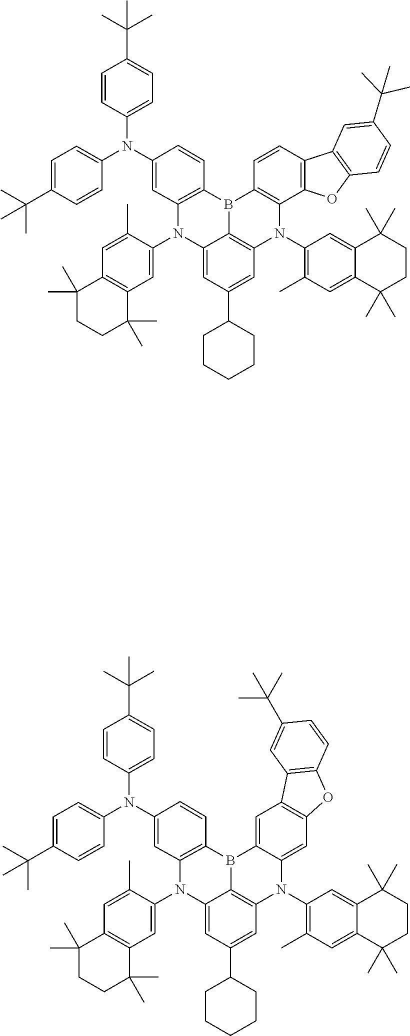

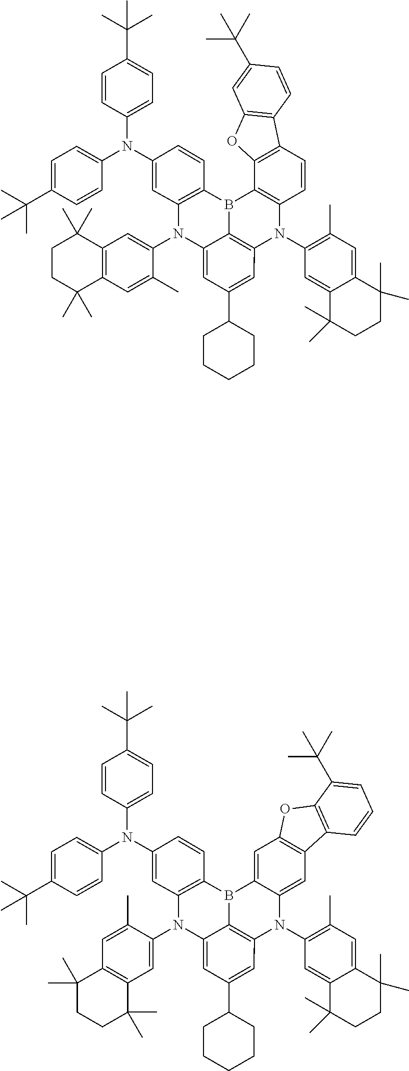

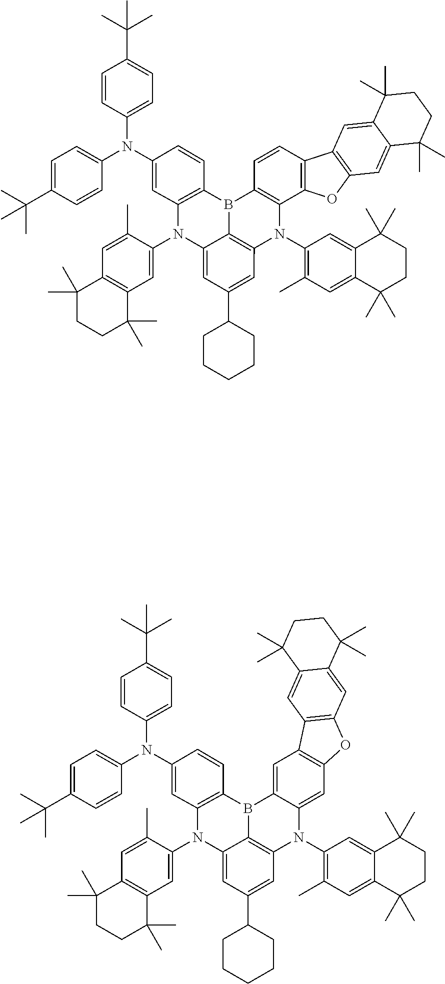

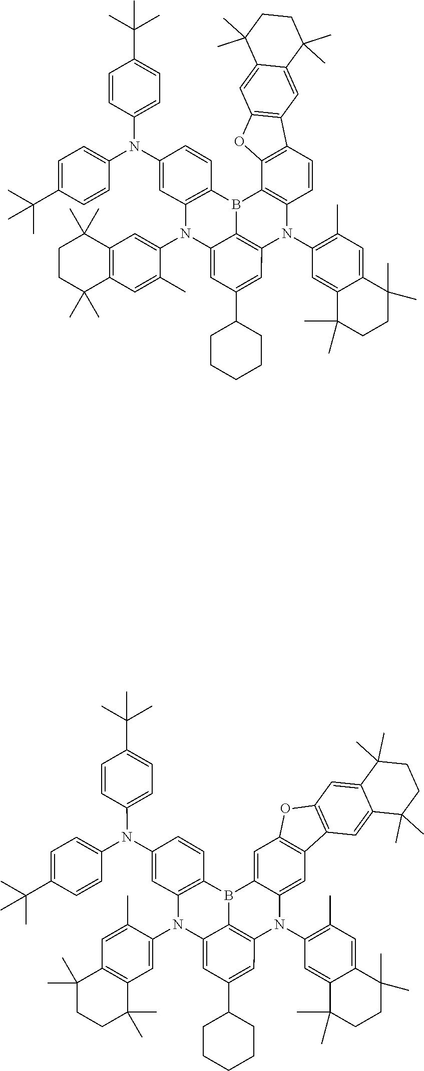

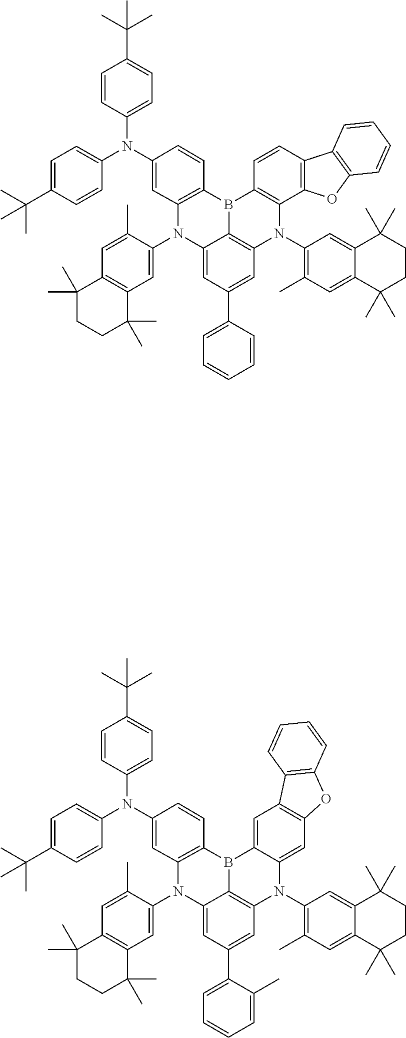 [SMILES: Cc1cc2c(cc1N1c3cc(N(c4ccc(C(C)(C)C)cc4)c4ccc(C(C)(C)C)cc4)ccc3B3c4ccc5c(oc6ccccc65)c4N(c4cc5c(cc4C)C(C)(C)CCC5(C)C)c4cc(-c5ccccc5)cc1c43)C(C)(C)CCC2(C)C ; Cc1ccccc1-c1cc2c3c(c1)N(c1cc4c(cc1C)C(C)(C)CCC4(C)C)c1cc4oc5ccccc5c4cc1B3c1ccc(N(c3ccc(C(C)(C)C)cc3)c3ccc(C(C)(C)C)cc3)cc1N2c1cc2c(cc1C)C(C)(C)CCC2(C)C]

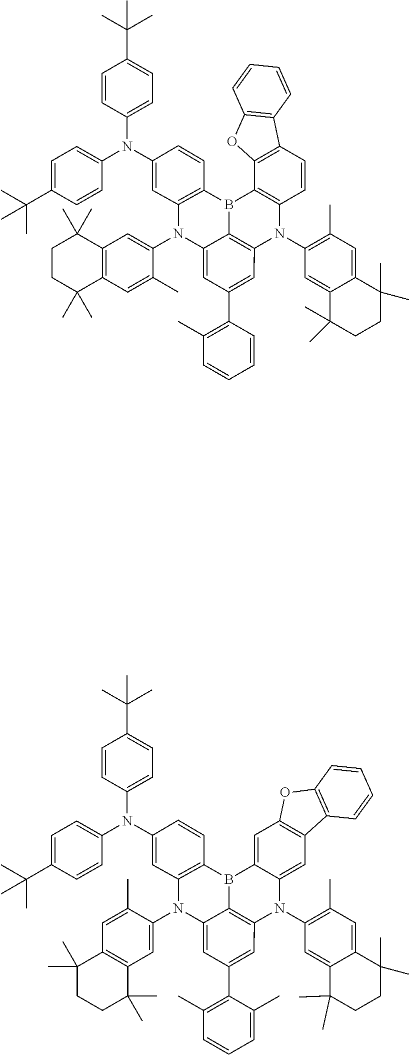

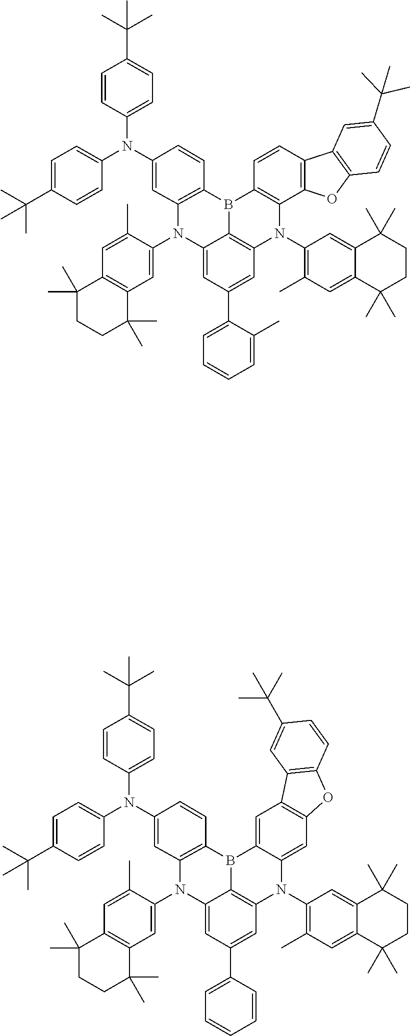

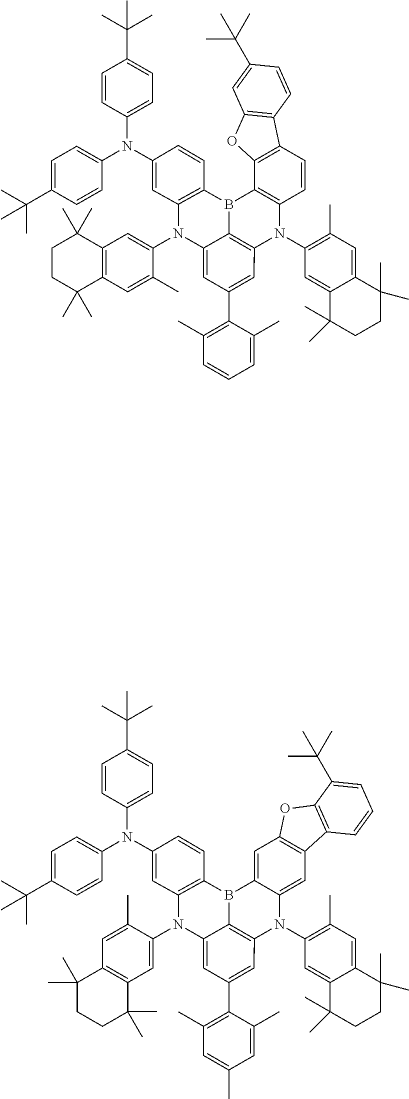

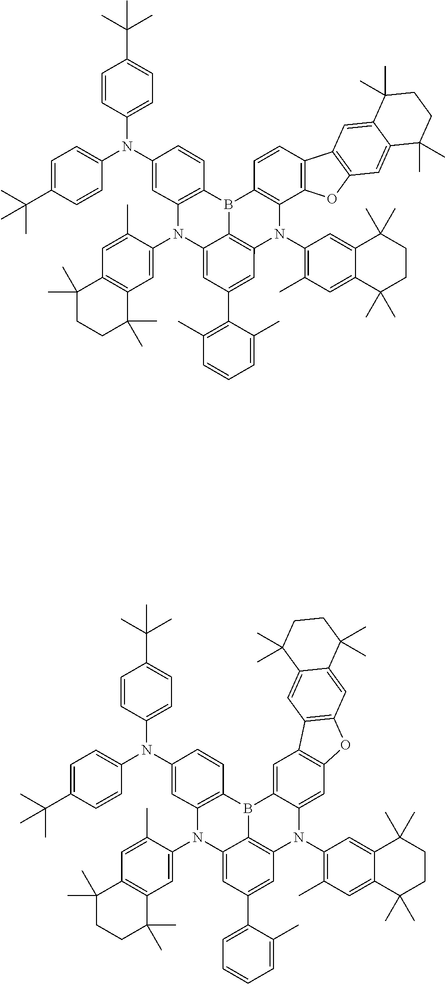

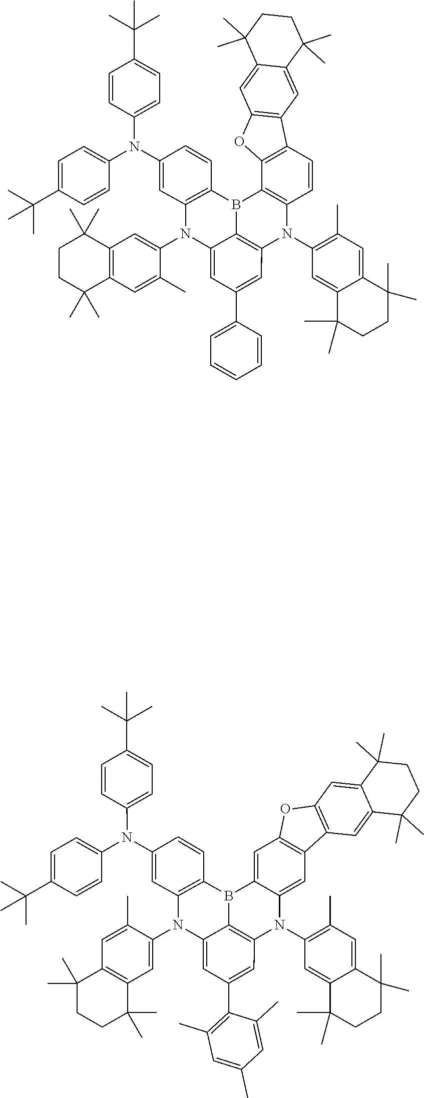

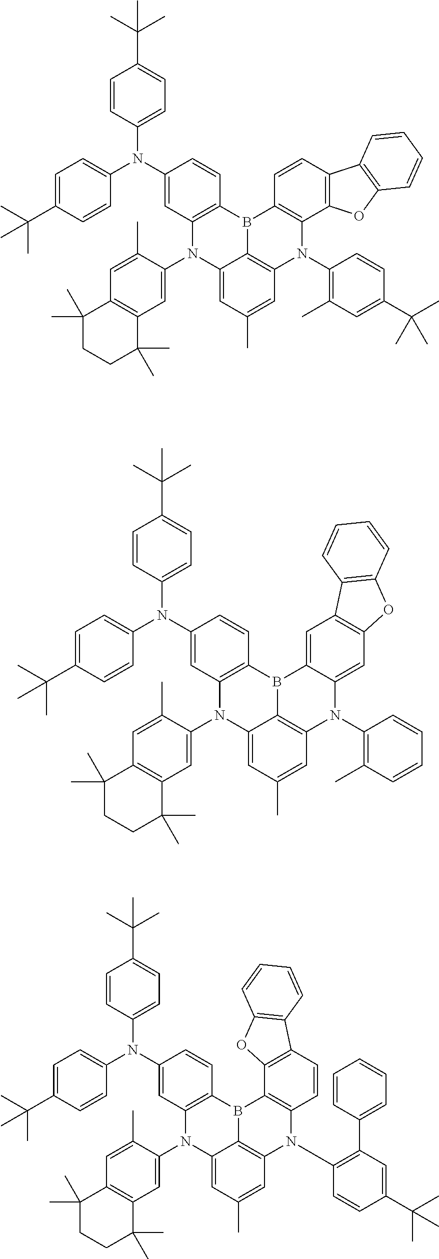

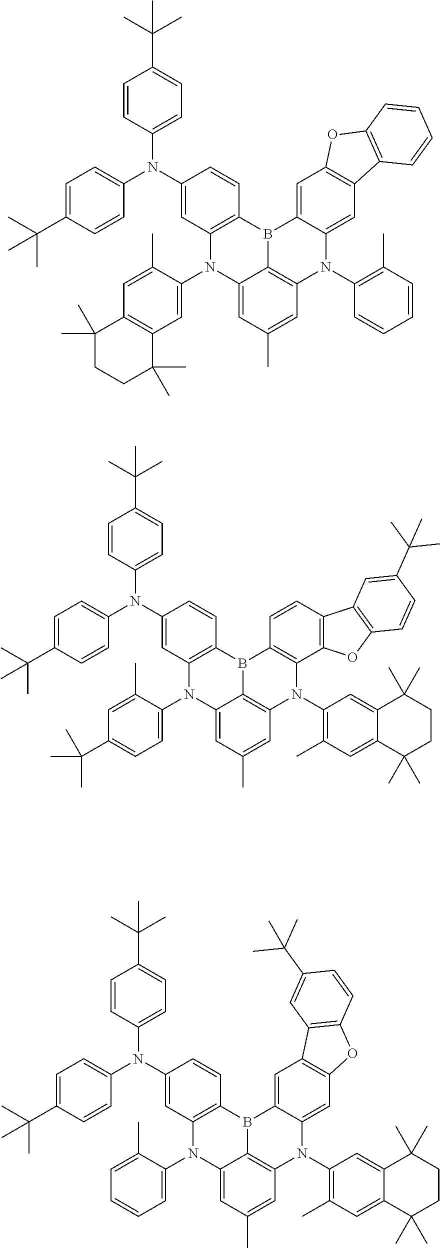

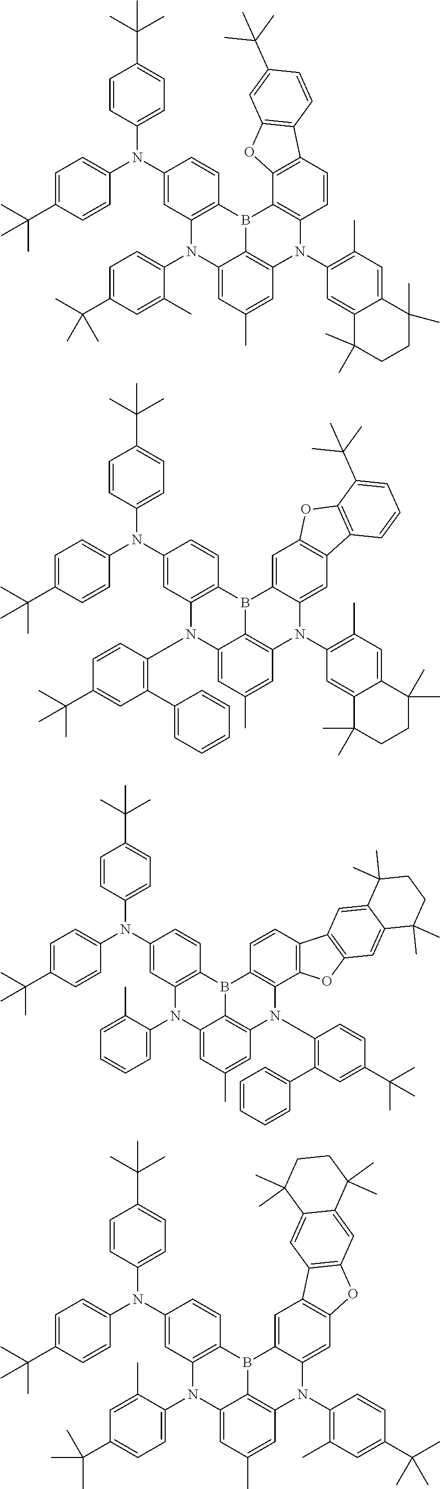

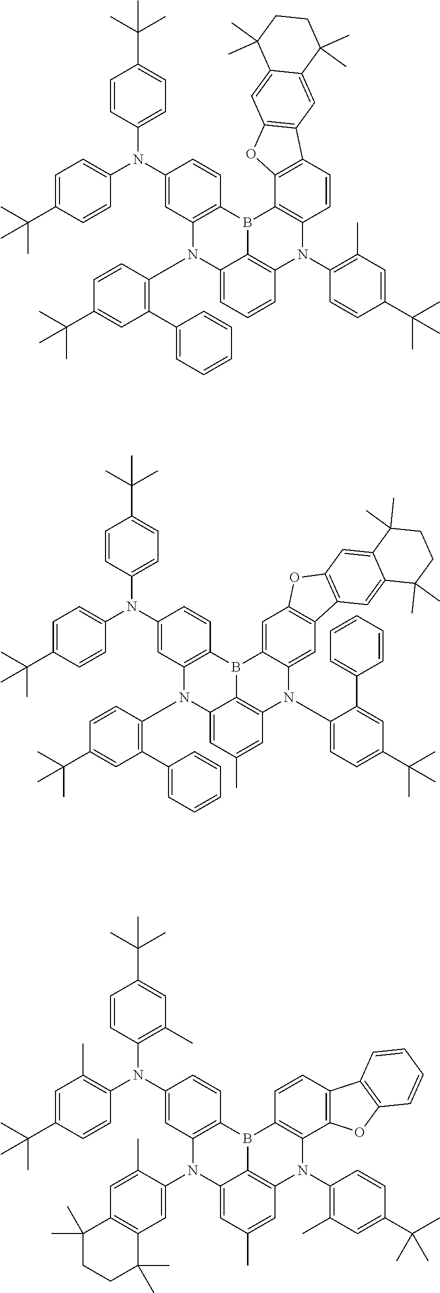

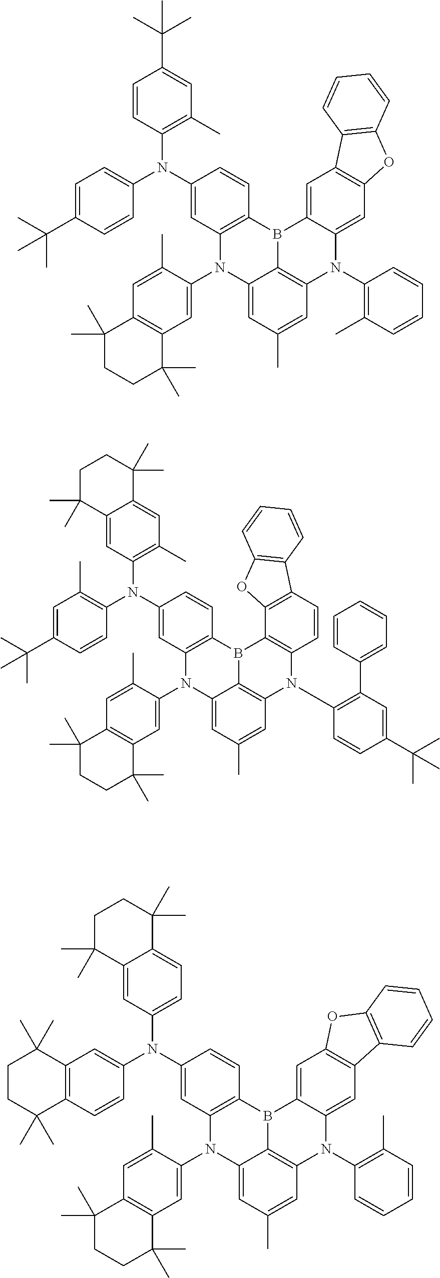 [SMILES: Cc1cc2c3c(c1)N(c1ccccc1C)c1cc4oc5ccccc5c4cc1B3c1ccc(N(c3ccc(C(C)(C)C)cc3)c3ccc(C(C)(C)C)cc3C)cc1N2c1cc2c(cc1C)C(C)(C)CCC2(C)C ; Cc1cc2c3c(c1)N(c1ccc(C(C)(C)C)cc1-c1ccccc1)c1ccc4c(oc5ccccc54)c1B3c1ccc(N(c3ccc(C(C)(C)C)cc3C)c3cc4c(cc3C)C(C)(C)CCC4(C)C)cc1N2c1cc2c(cc1C)C(C)(C)CCC2(C)C ; Cc1cc2c3c(c1)N(c1ccccc1C)c1cc4c(cc1B3c1ccc(N(c3ccc5c(c3)C(C)(C)CCC5(C)C)c3ccc5c(c3)C(C)(C)CCC5(C)C)cc1N2c1cc2c(cc1C)C(C)(C)CCC2(C)C)oc1ccccc14]

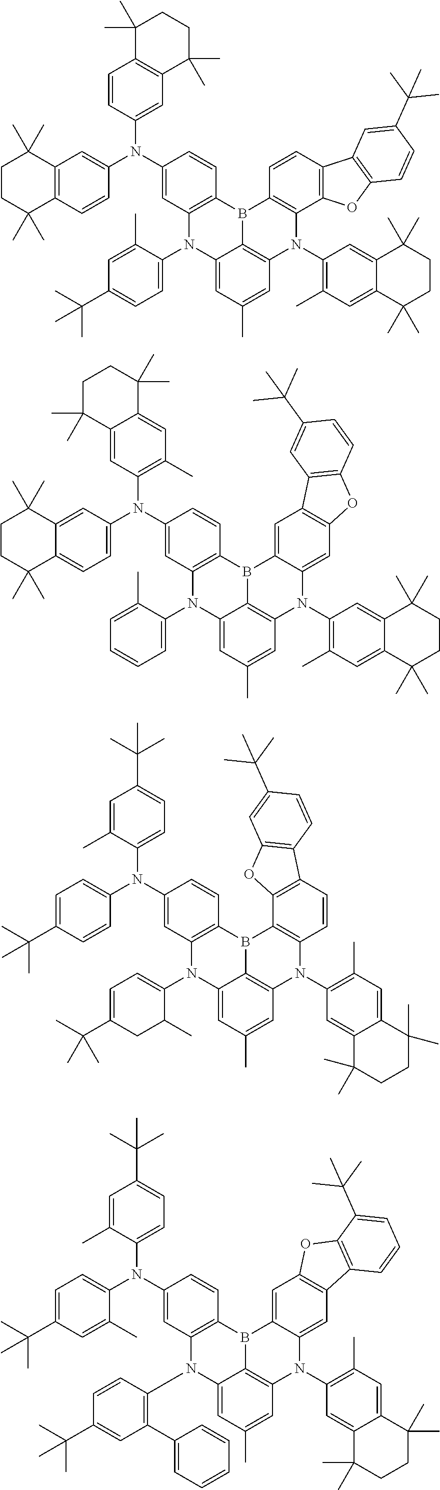

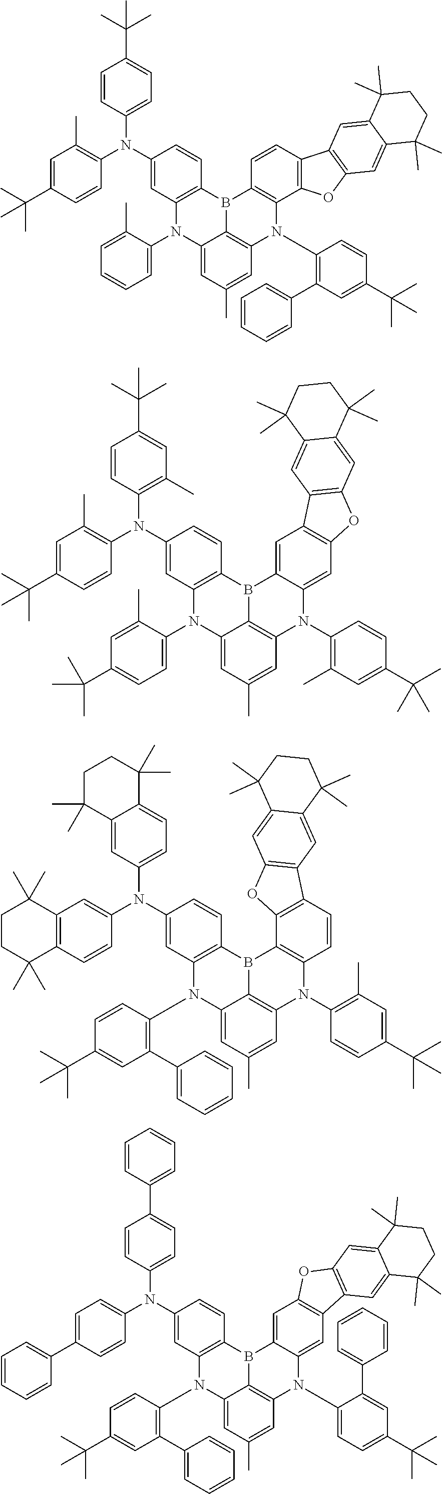

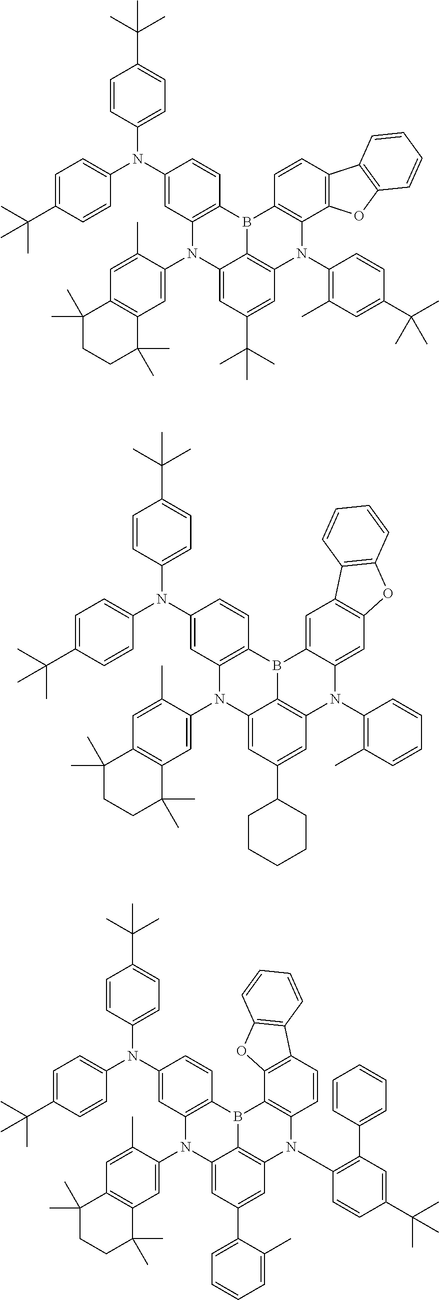

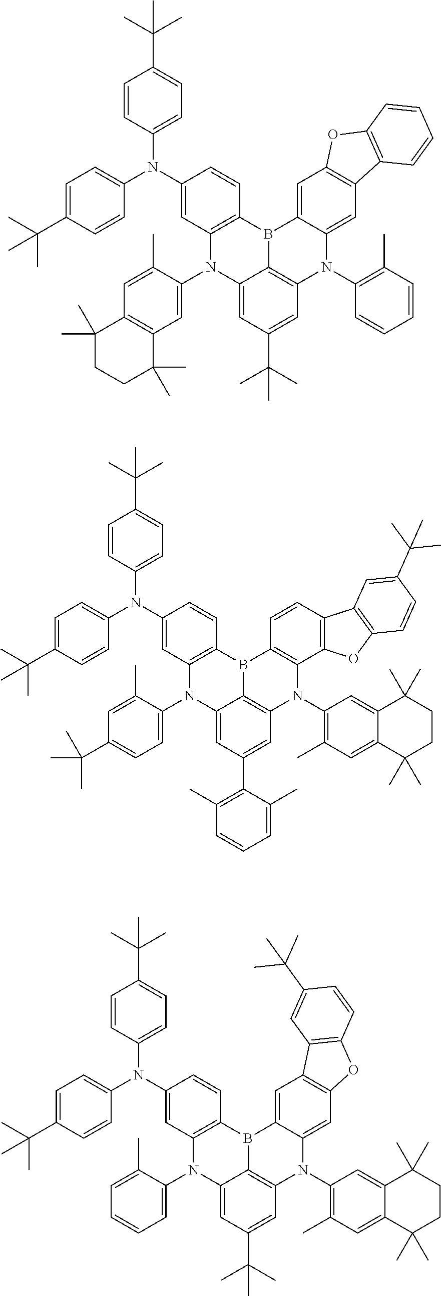

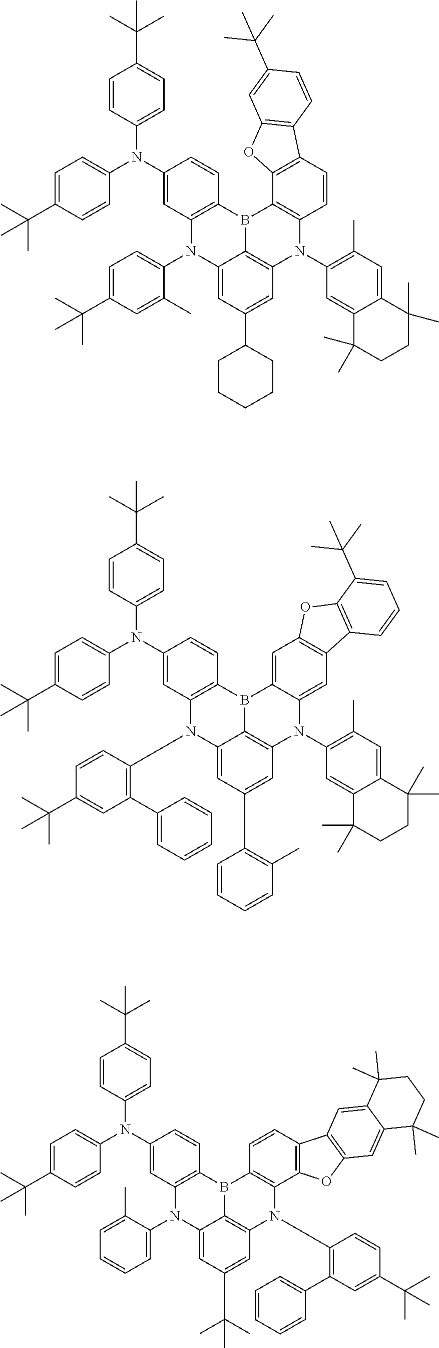

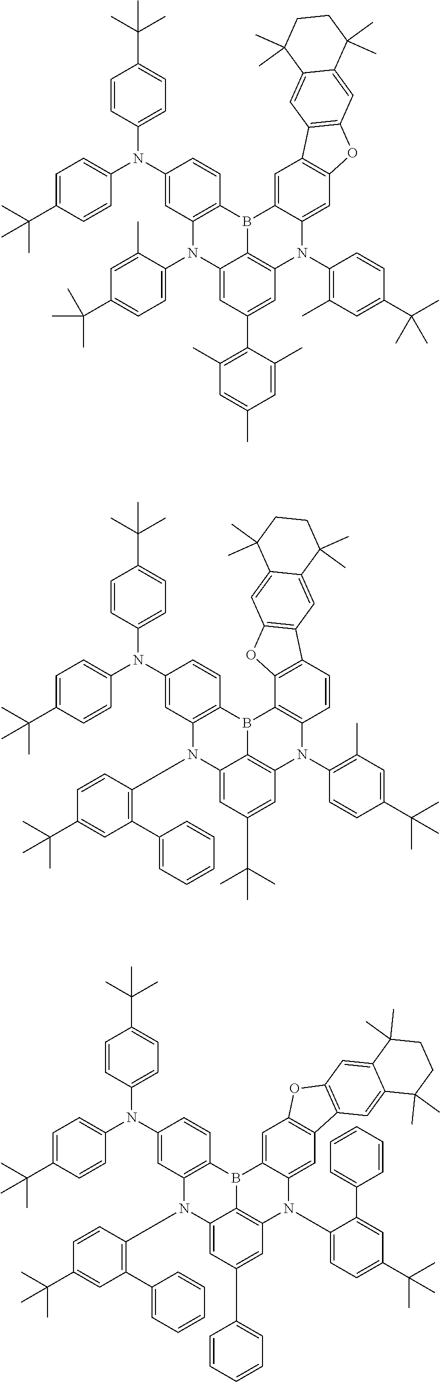

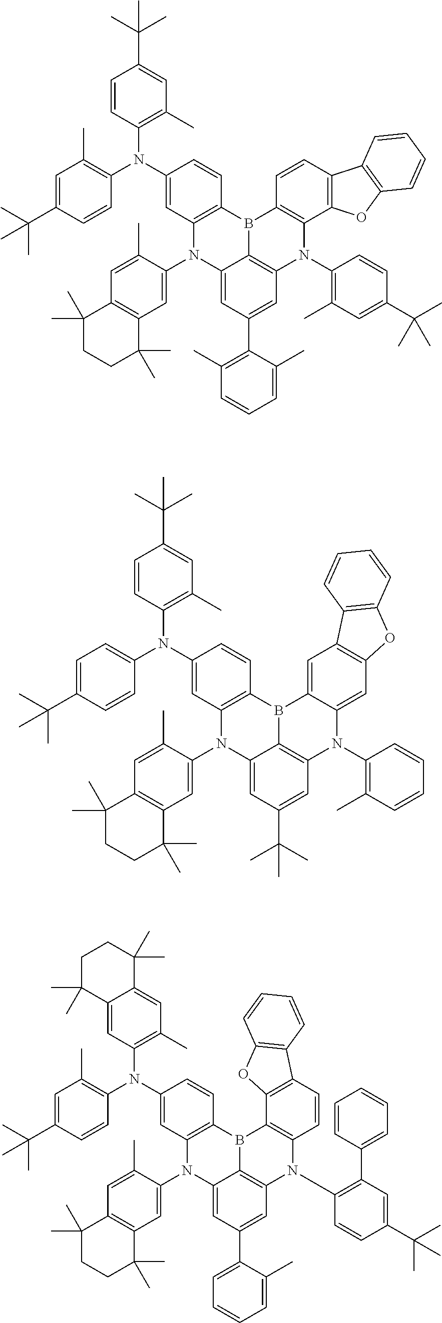

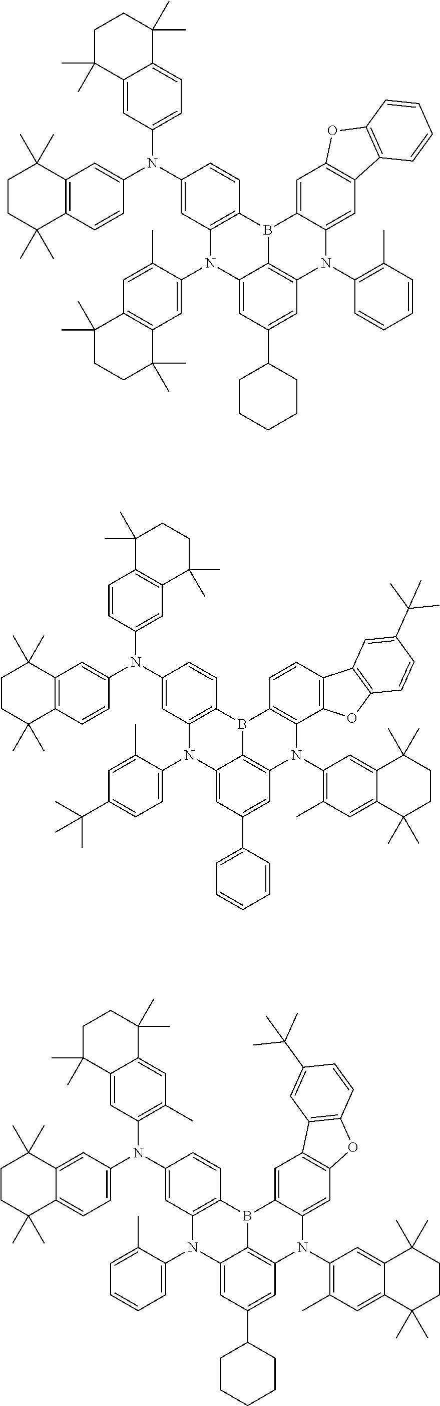 [SMILES: Cc1ccccc1N1c2cc3c(cc2B2c4ccc(N(c5ccc6c(c5)C(C)(C)CCC6(C)C)c5ccc6c(c5)C(C)(C)CCC6(C)C)cc4N(c4cc5c(cc4C)C(C)(C)CCC5(C)C)c4cc(C5CCCCC5)cc1c42)oc1ccccc13 ; Cc1cc(C(C)(C)C)ccc1N1c2cc(N(c3ccc4c(c3)C(C)(C)CCC4(C)C)c3ccc4c(c3)C(C)(C)CCC4(C)C)ccc2B2c3ccc4c(oc5ccc(C(C)(C)C)cc54)c3N(c3cc4c(cc3C)C(C)(C)CCC4(C)C)c3cc(-c4ccccc4)cc1c32 ; Cc1cc2c(cc1N(c1ccc3c(c1)N(c1ccccc1C)c1cc(C4CCCCC4)cc4c1B3c1cc3c(cc1N4c1cc4c(cc1C)C(C)(C)CCC4(C)C)oc1ccc(C(C)(C)C)cc13)c1ccc3c(c1)C(C)(C)CCC3(C)C)C(C)(C)CCC2(C)C]

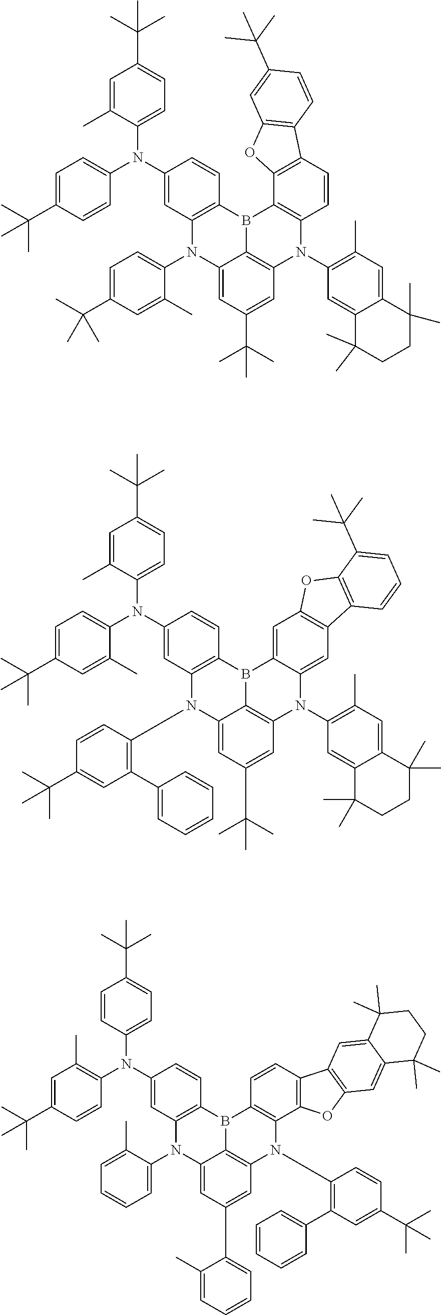

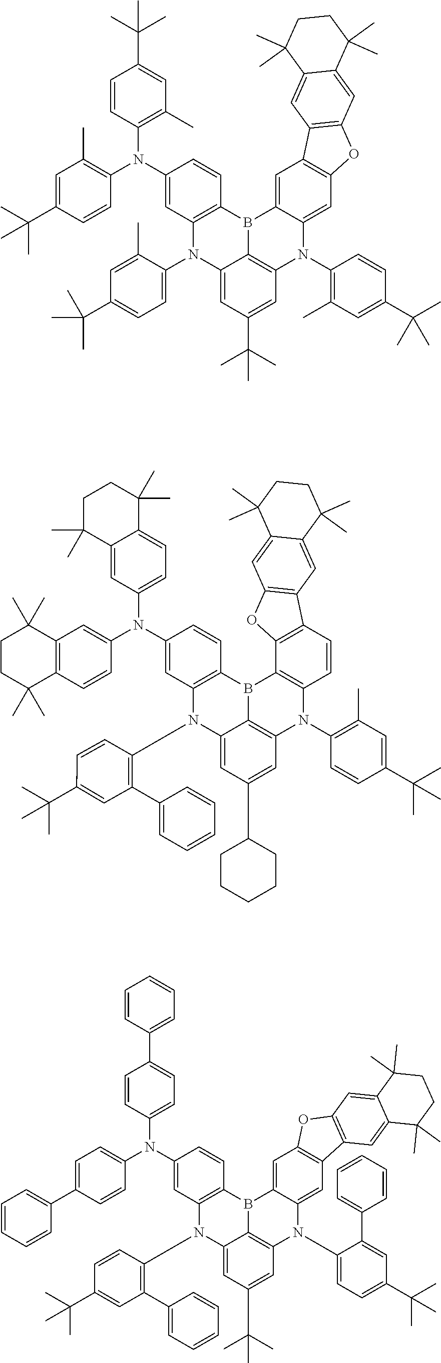

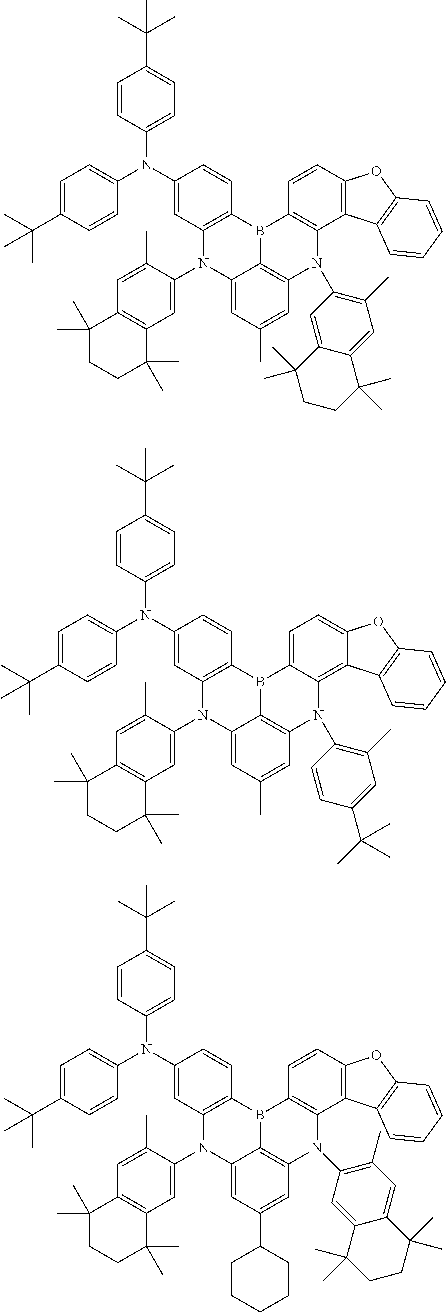

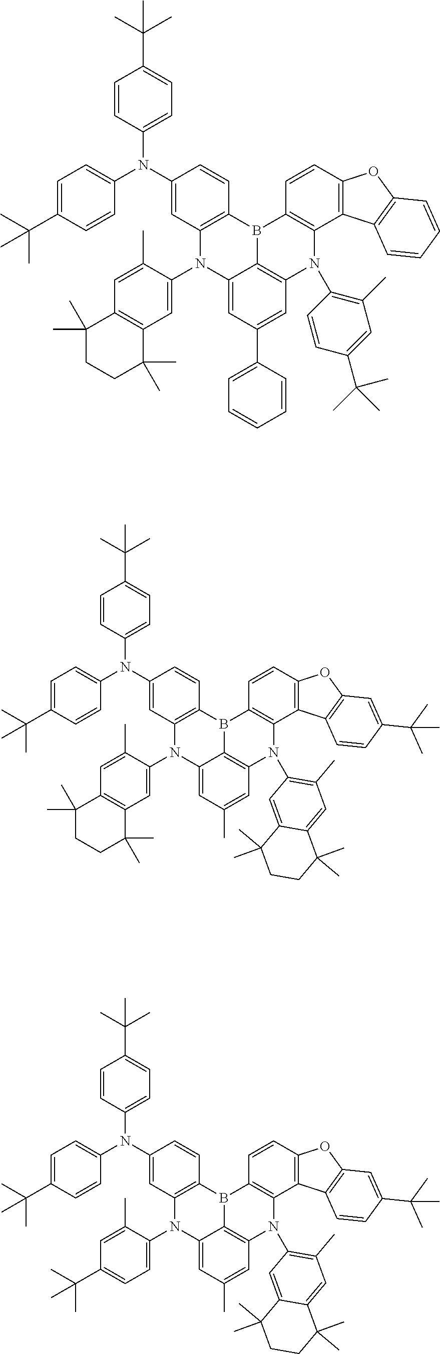

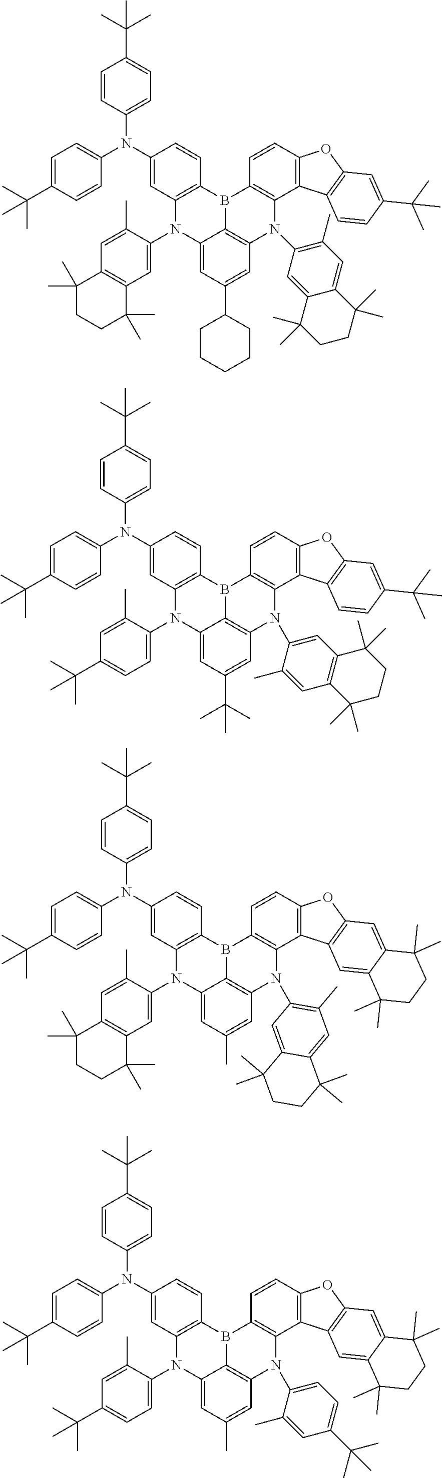

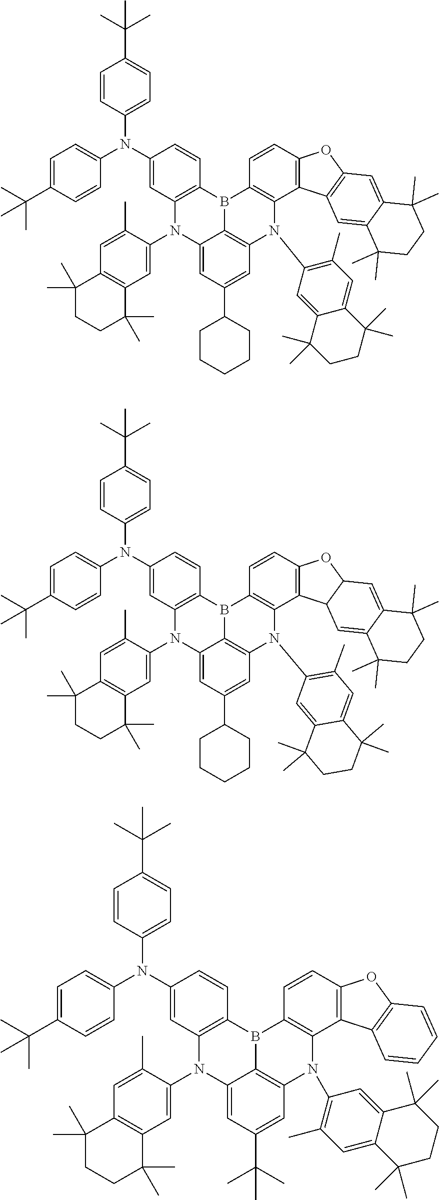

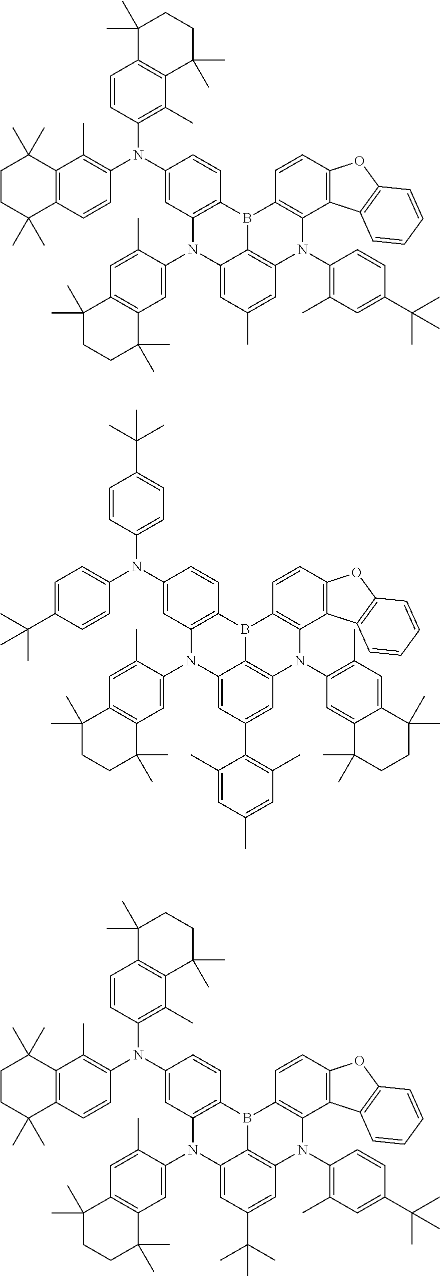

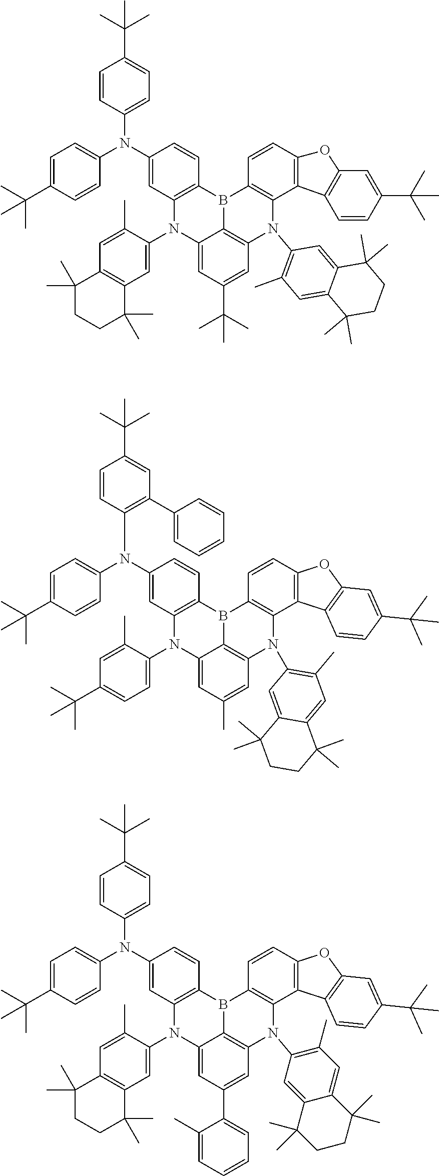

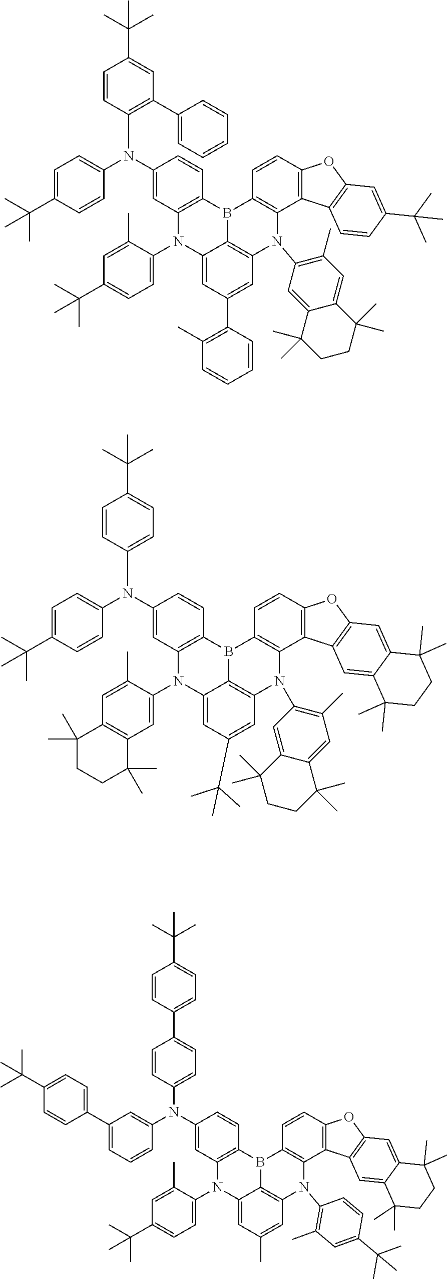

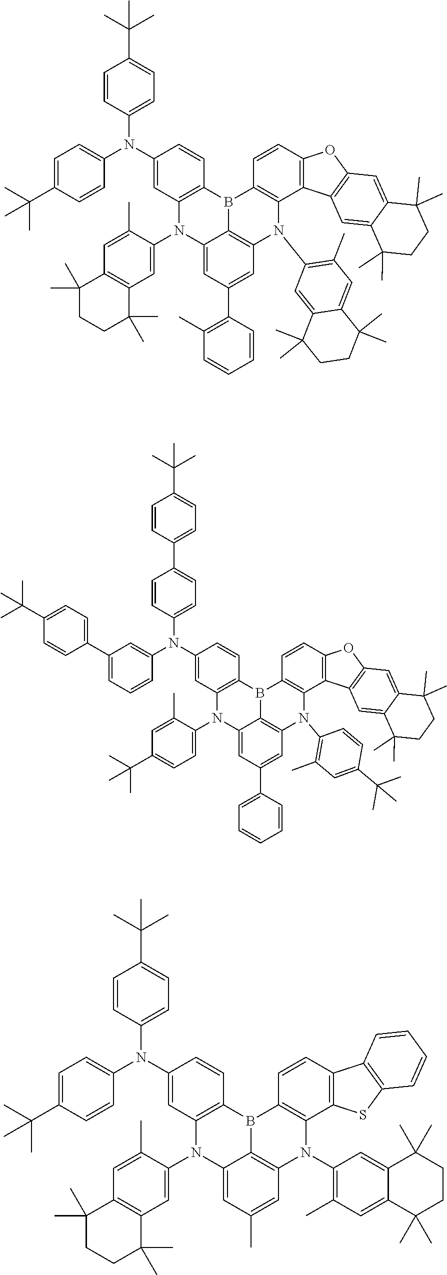

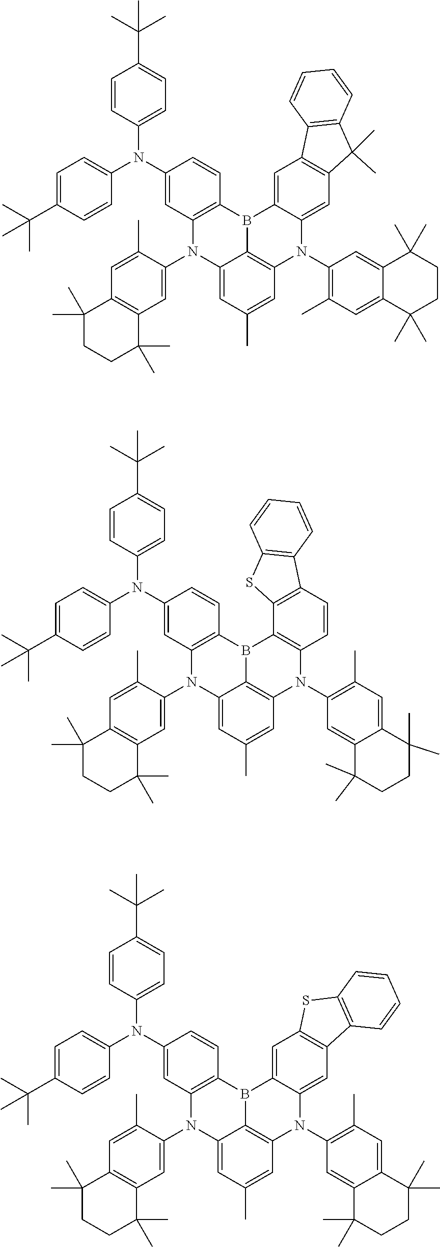

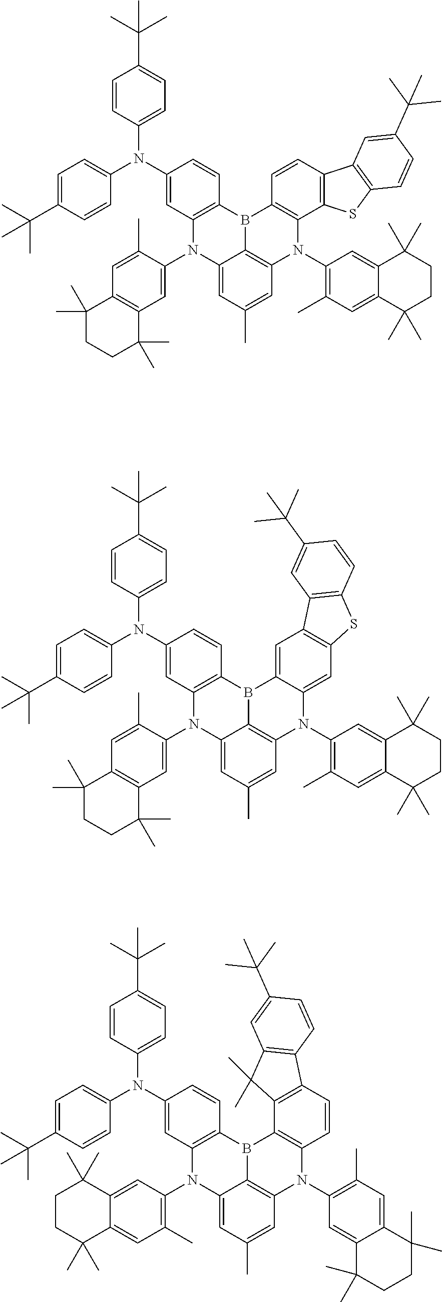

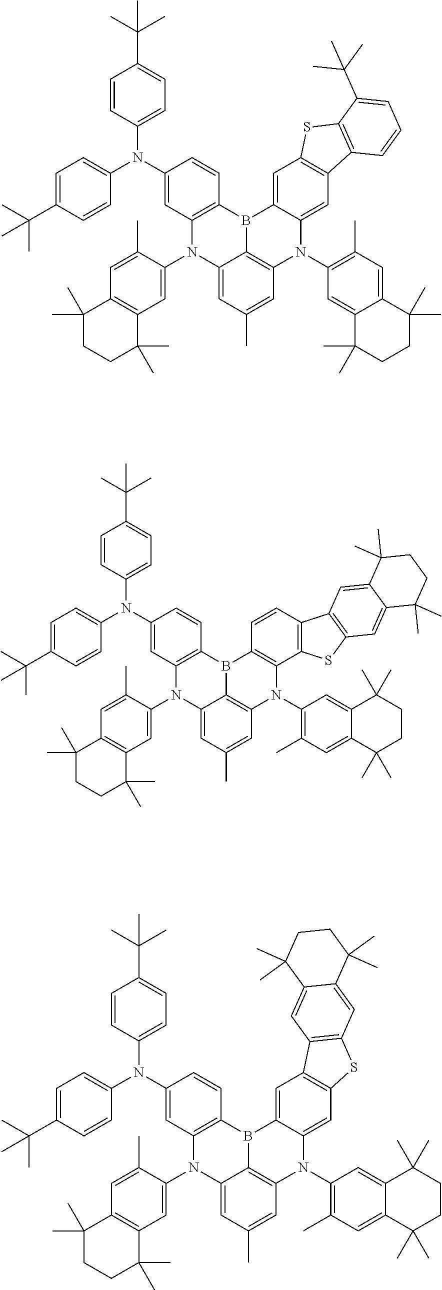

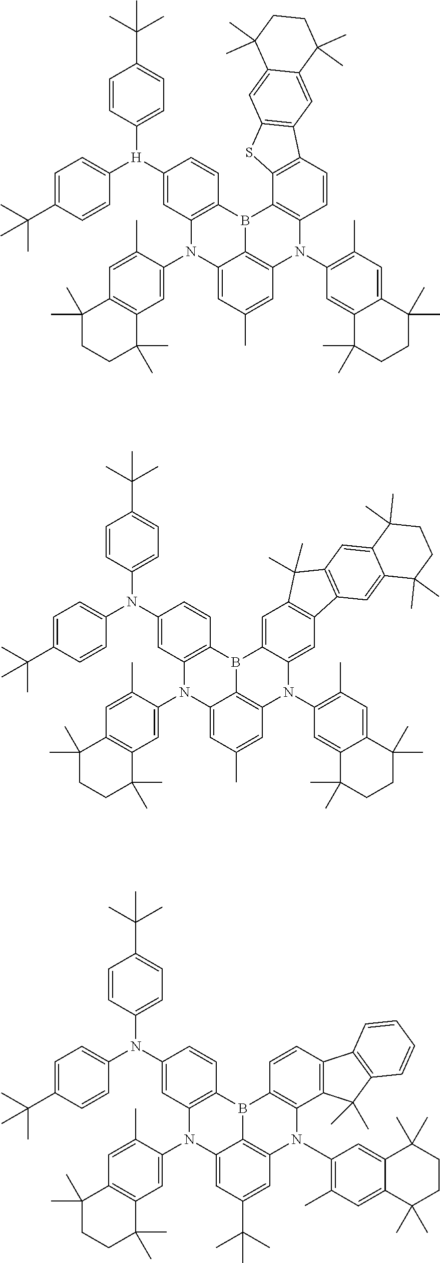

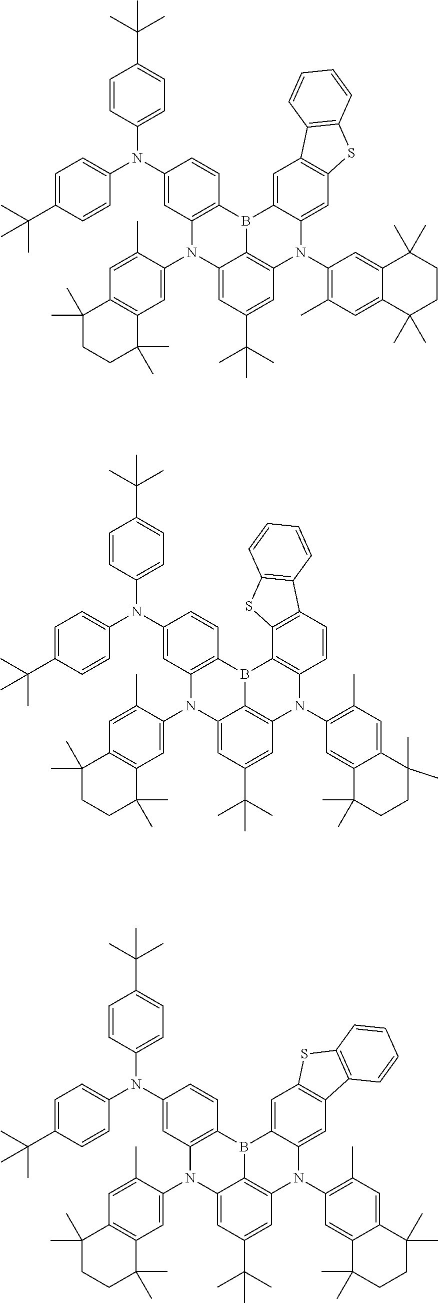

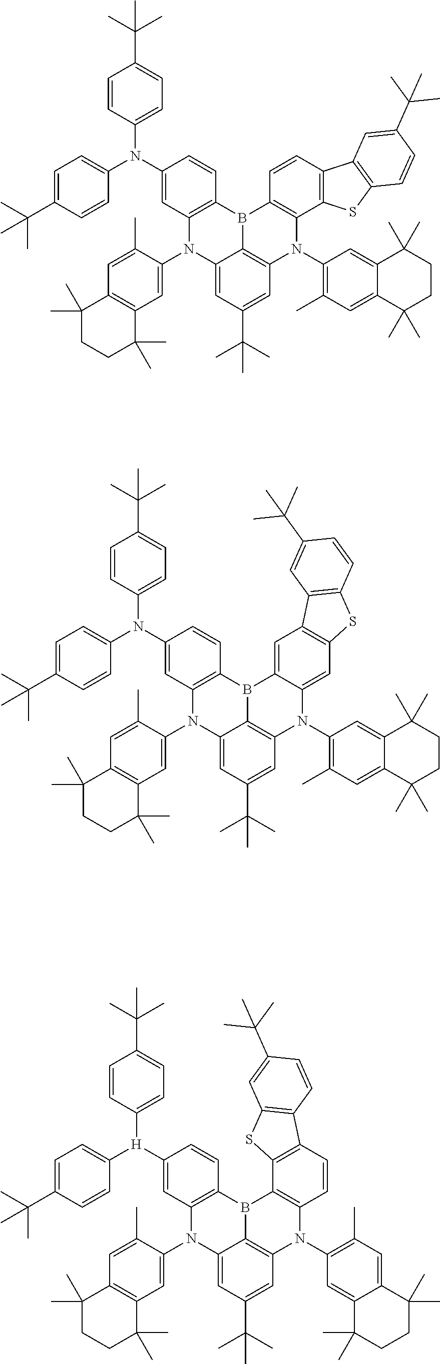

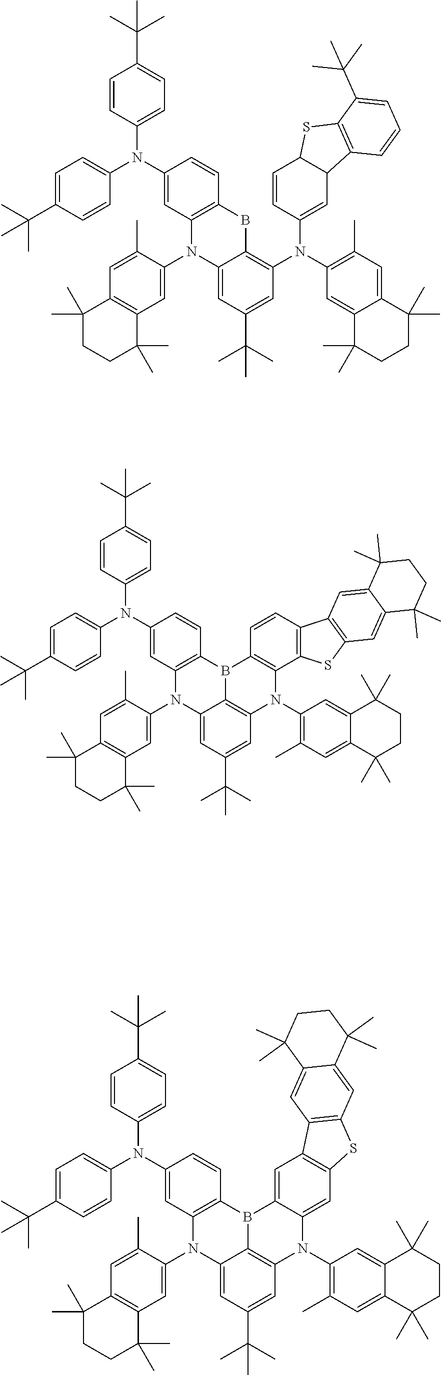

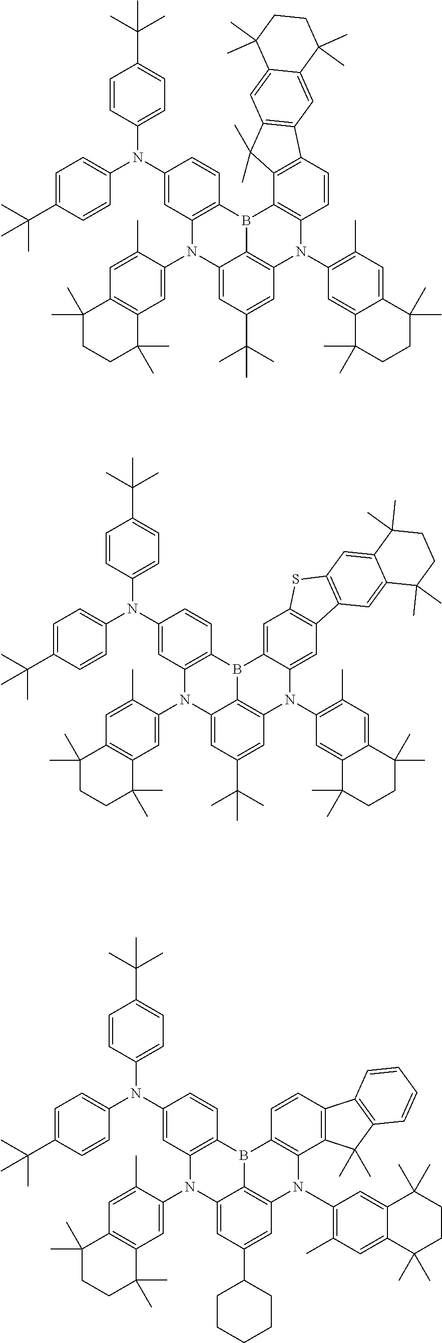

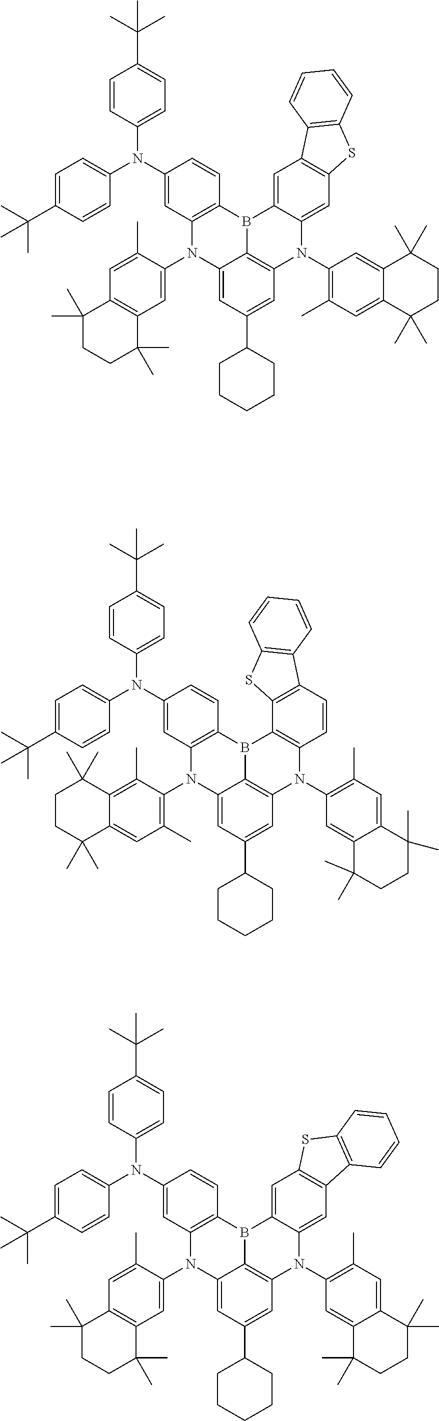

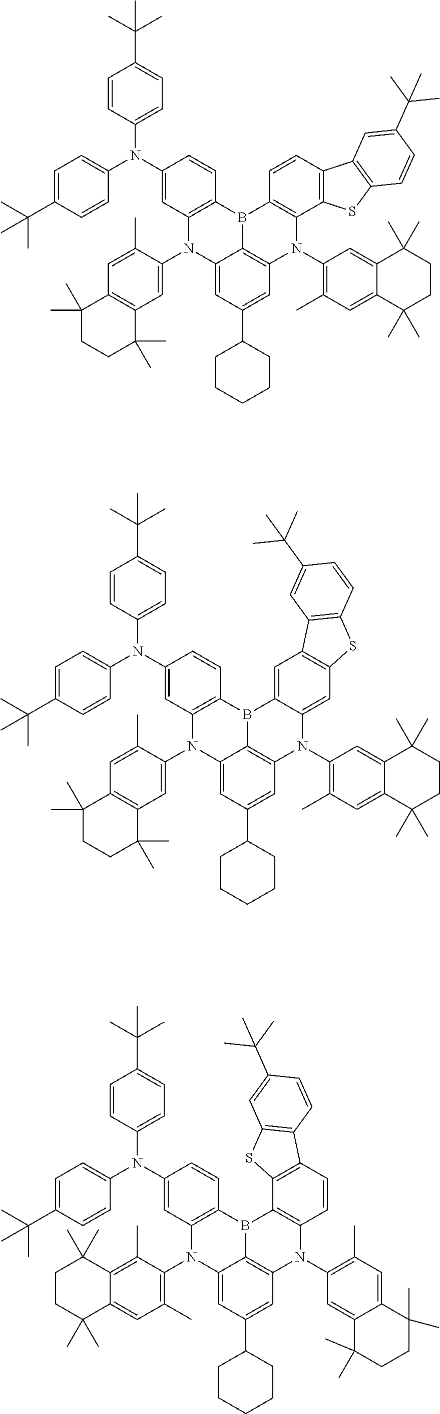

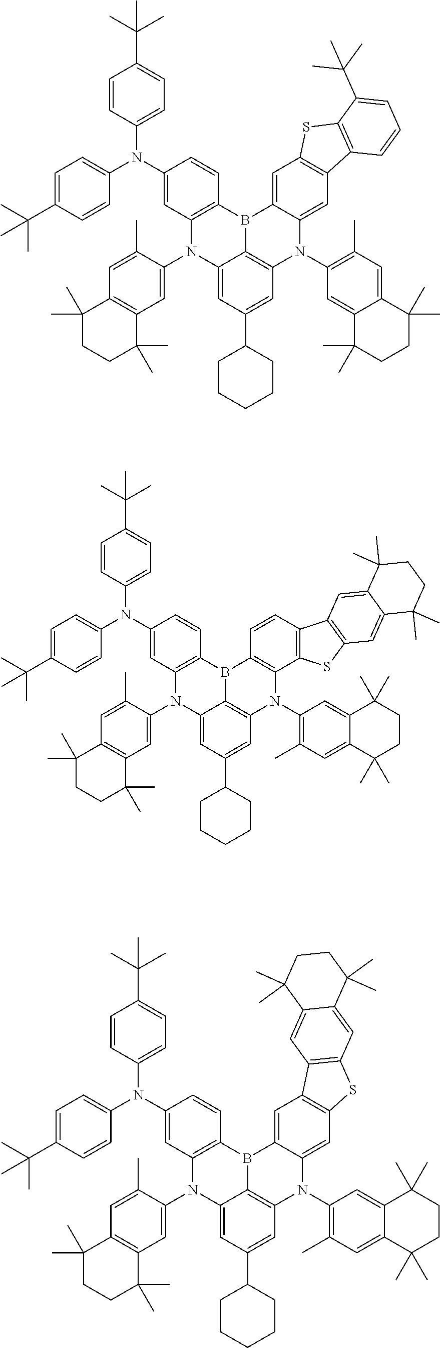

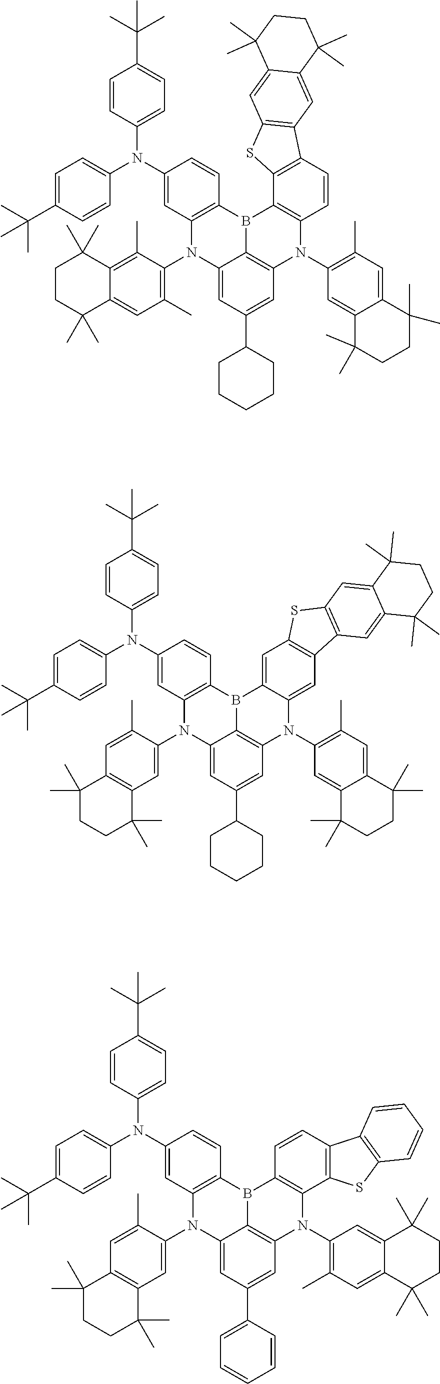

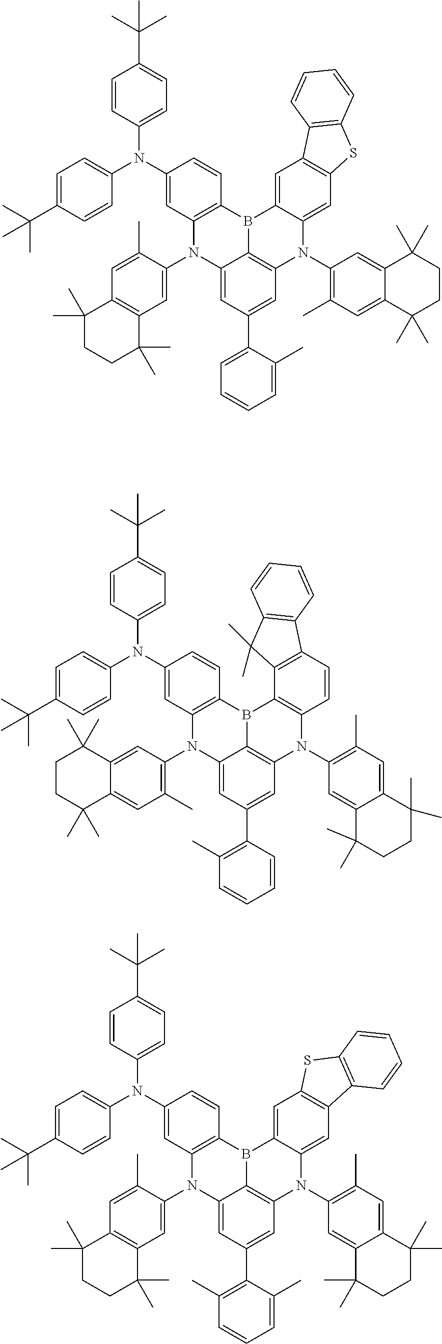

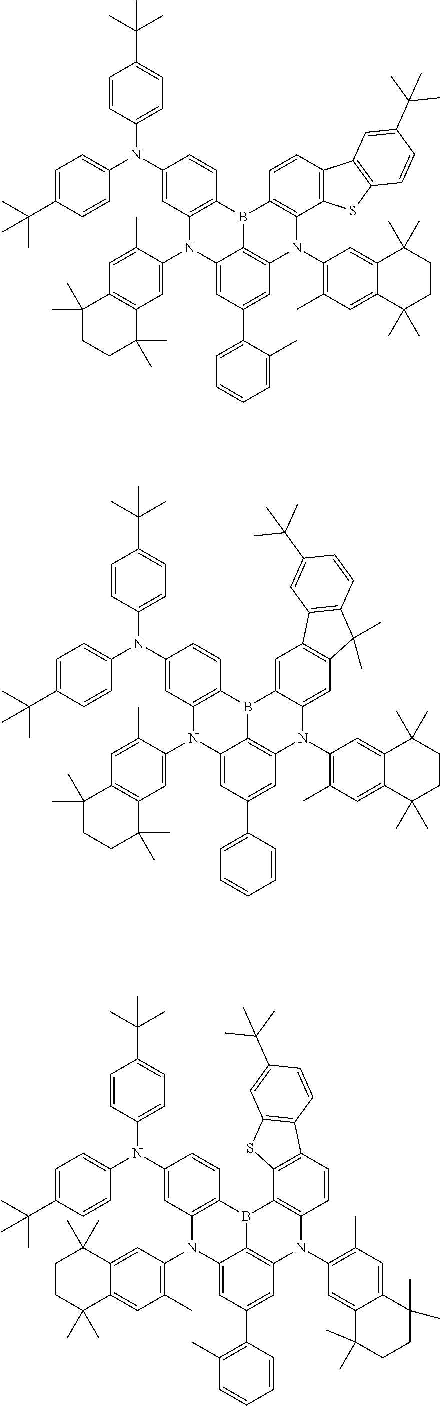

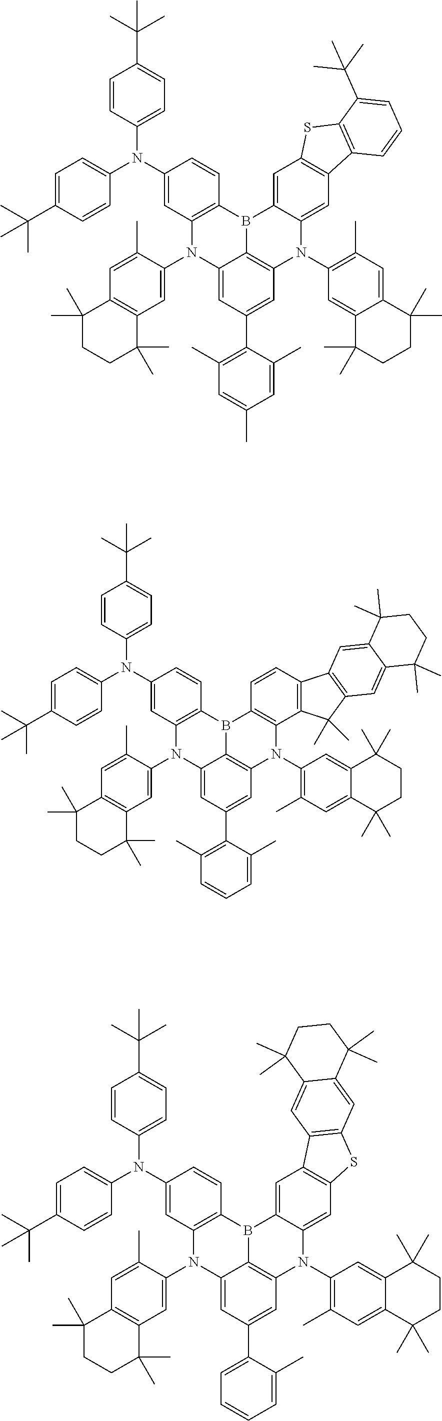

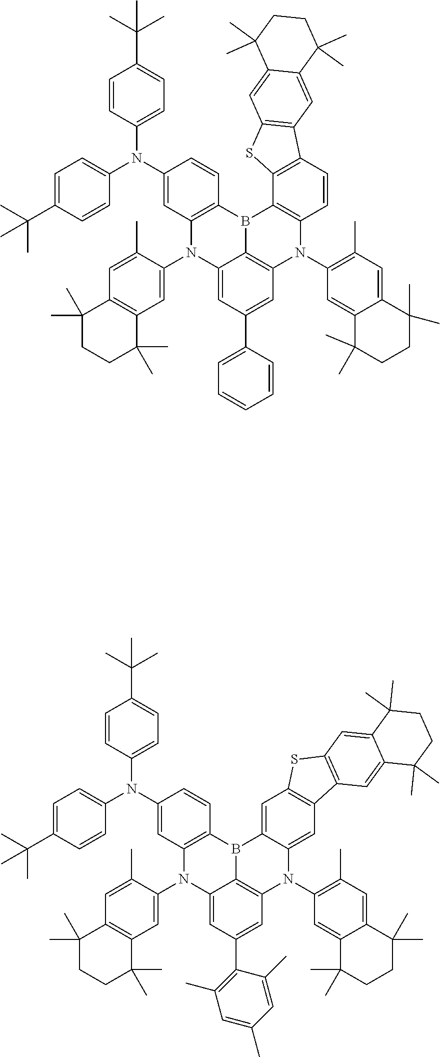

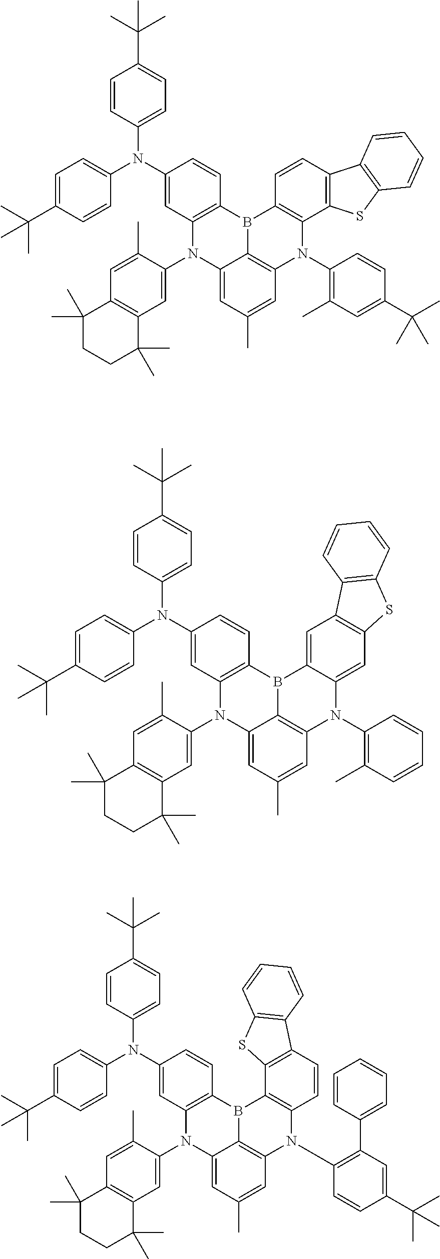

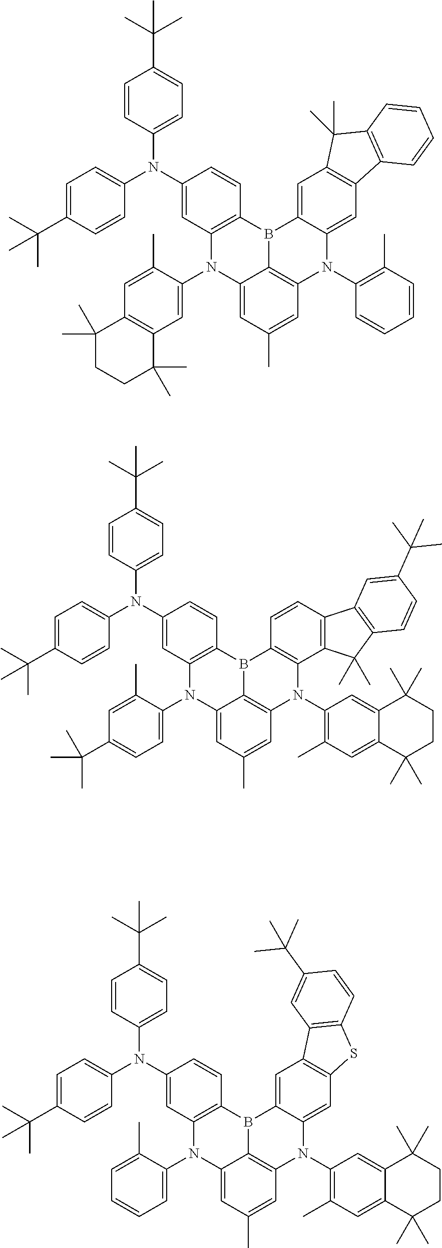

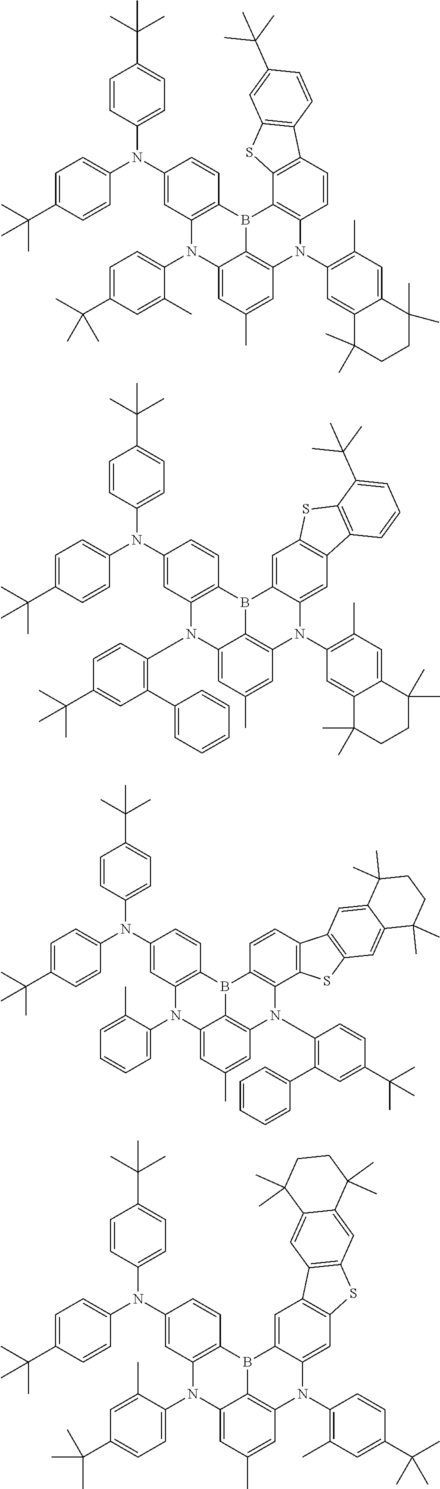

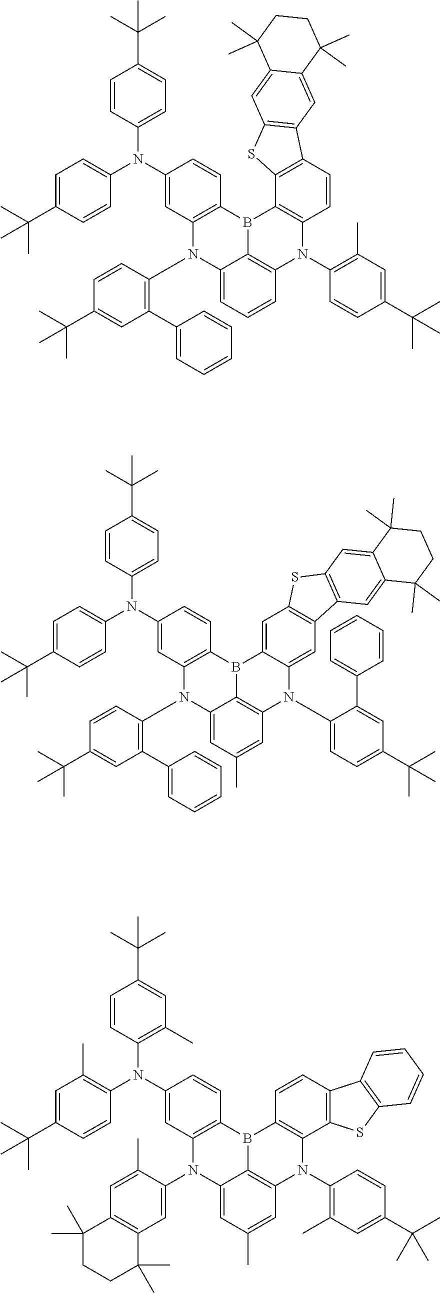

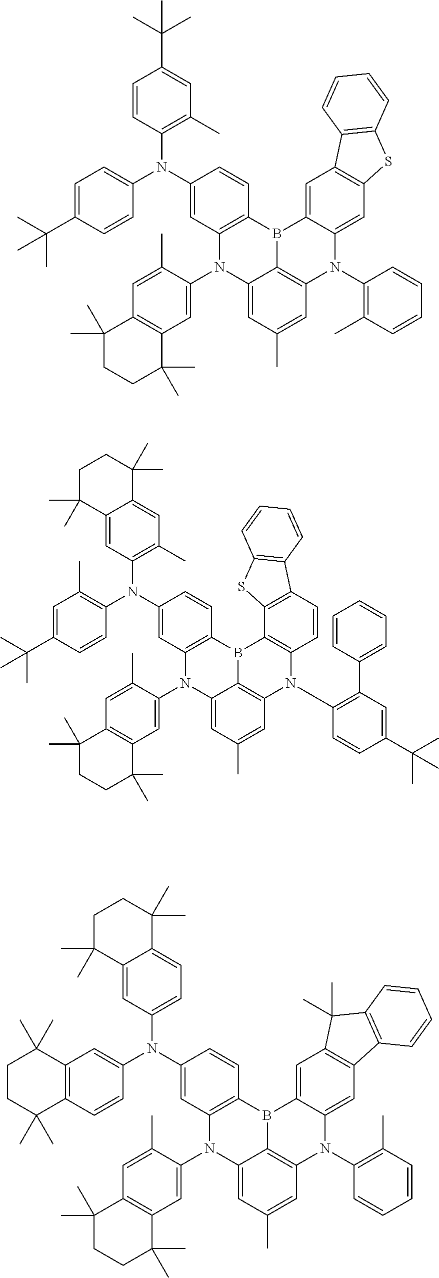 [SMILES: Cc1cc2c3c(c1)N(c1ccccc1C)c1cc4sc5ccccc5c4cc1B3c1ccc(N(c3ccc(C(C)(C)C)cc3)c3ccc(C(C)(C)C)cc3C)cc1N2c1cc2c(cc1C)C(C)(C)CCC2(C)C ; Cc1cc2c3c(c1)N(c1ccc(C(C)(C)C)cc1-c1ccccc1)c1ccc4c(sc5ccccc54)c1B3c1ccc(N(c3ccc(C(C)(C)C)cc3C)c3cc4c(cc3C)C(C)(C)CCC4(C)C)cc1N2c1cc2c(cc1C)C(C)(C)CCC2(C)C ; Cc1cc2c3c(c1)N(c1ccccc1C)c1cc4c(cc1B3c1ccc(N(c3ccc5c(c3)C(C)(C)CCC5(C)C)c3ccc5c(c3)C(C)(C)CCC5(C)C)cc1N2c1cc2c(cc1C)C(C)(C)CCC2(C)C)C(C)(C)c1ccccc1-4]

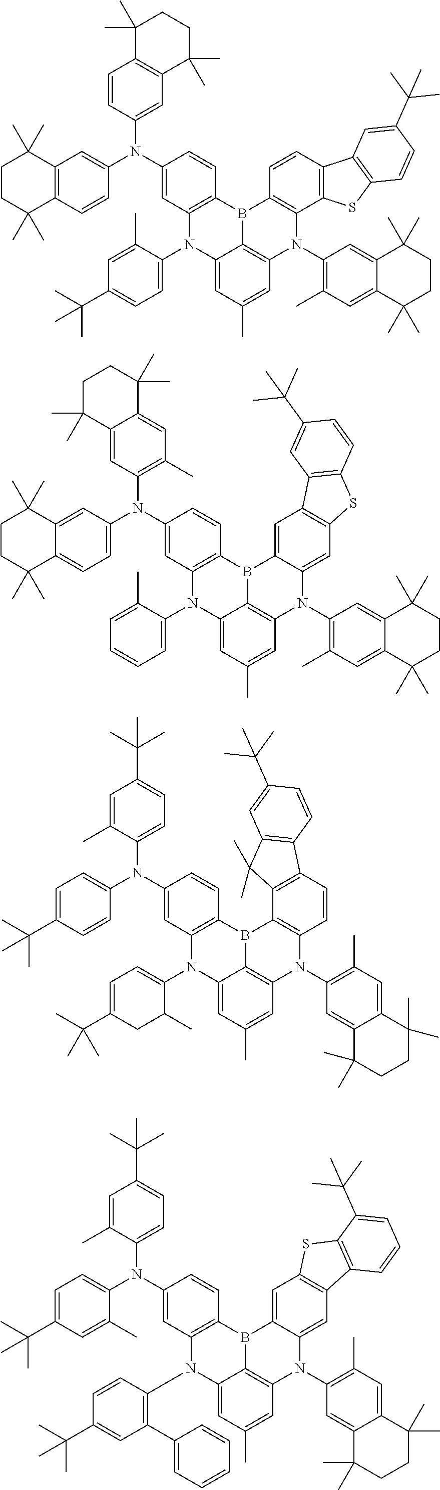

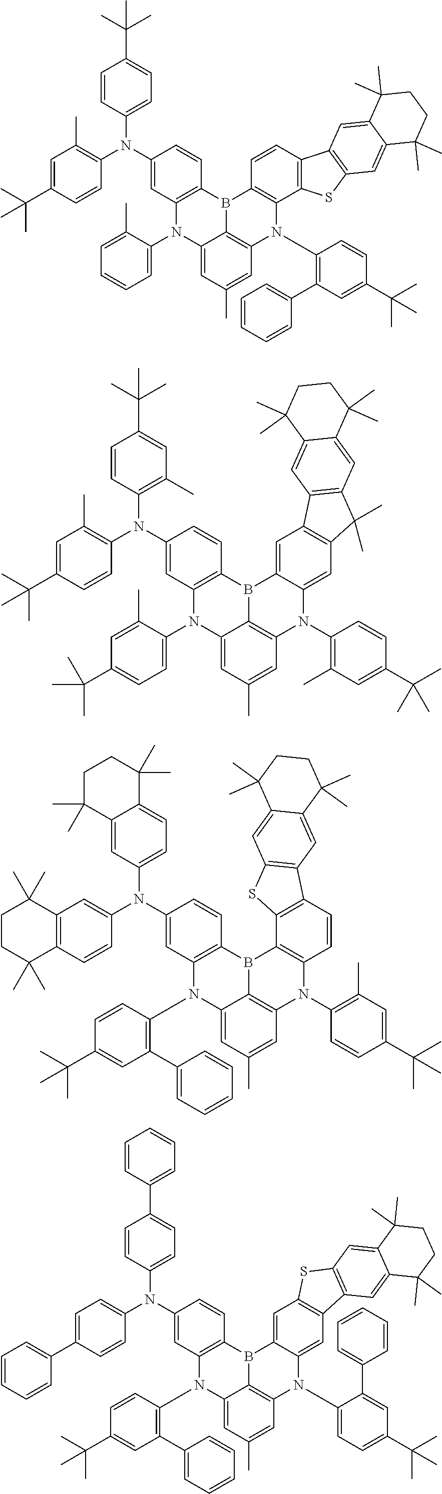

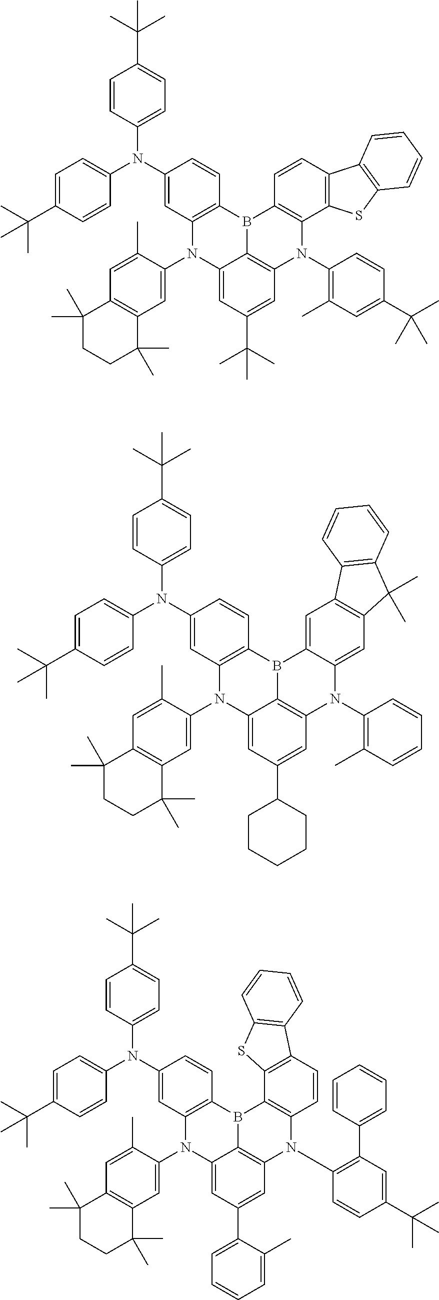

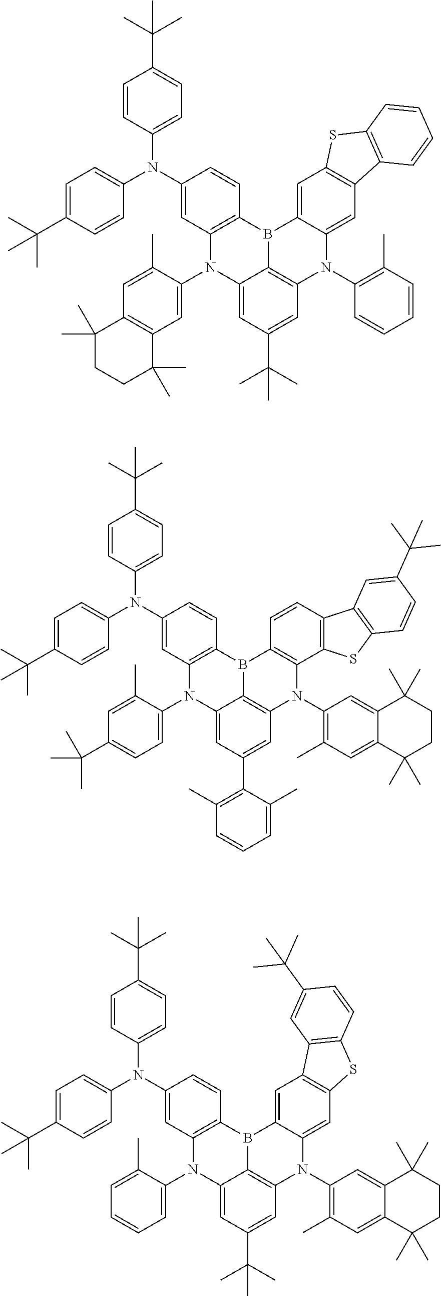

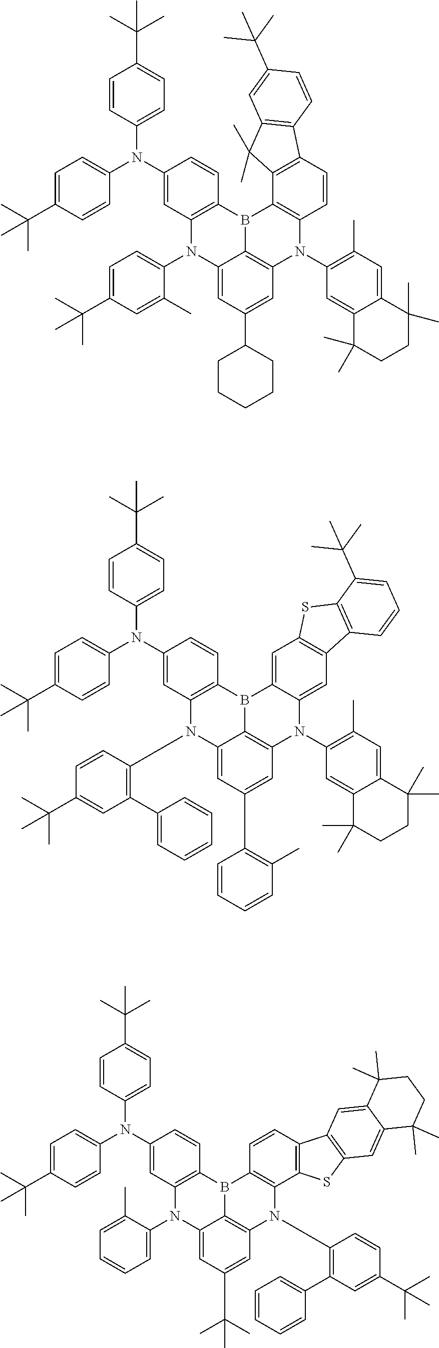

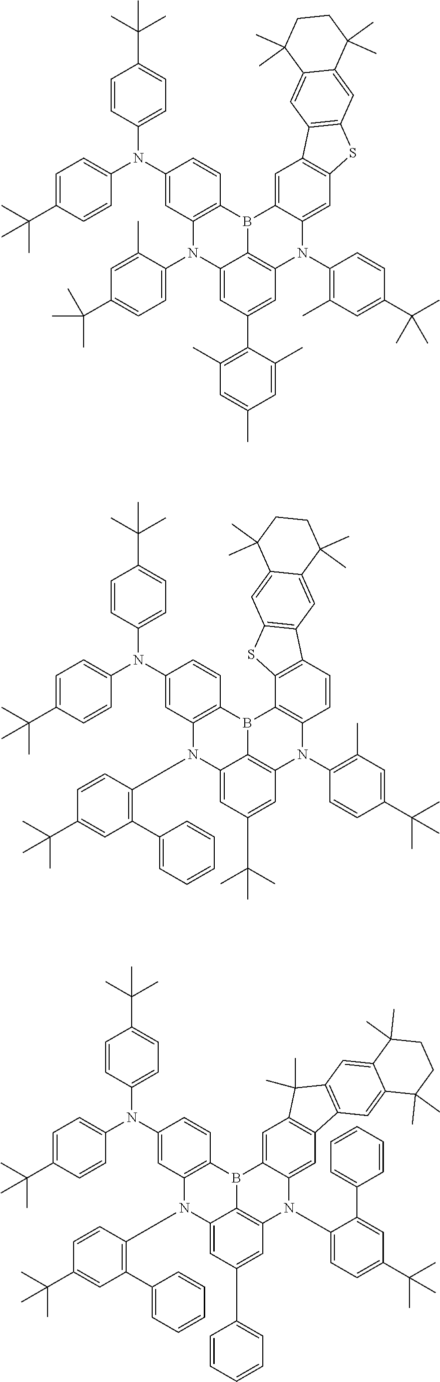

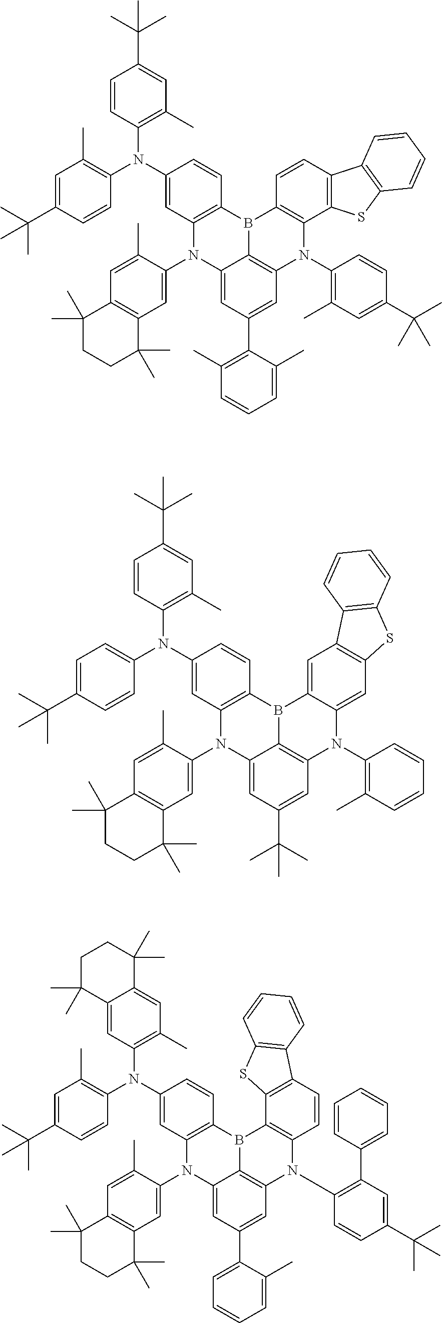

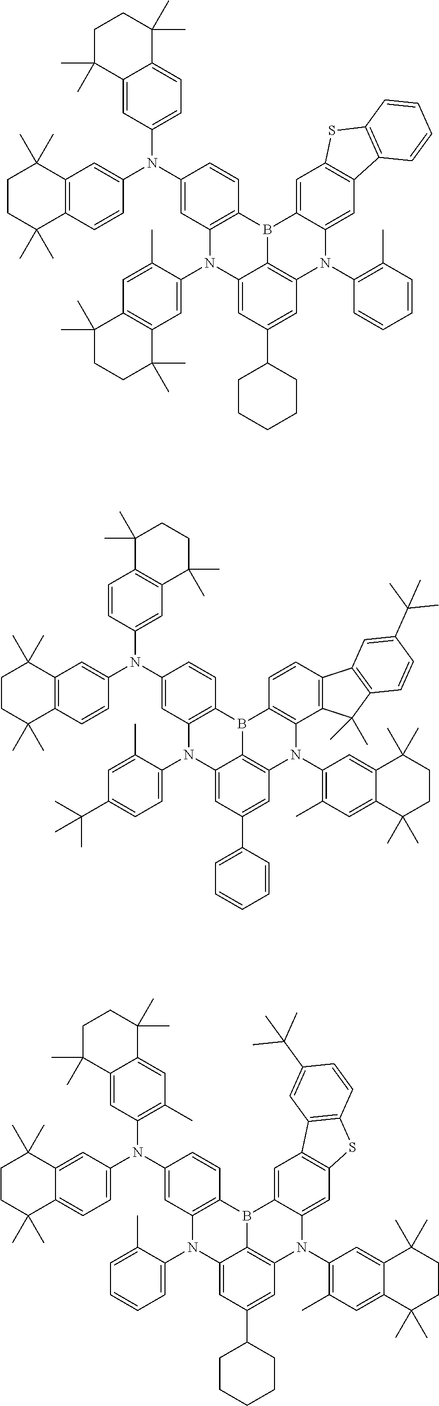 [SMILES: Cc1ccccc1N1c2cc3c(cc2B2c4ccc(N(c5ccc6c(c5)C(C)(C)CCC6(C)C)c5ccc6c(c5)C(C)(C)CCC6(C)C)cc4N(c4cc5c(cc4C)C(C)(C)CCC5(C)C)c4cc(C5CCCCC5)cc1c42)sc1ccccc13 ; Cc1cc(C(C)(C)C)ccc1N1c2cc(N(c3ccc4c(c3)C(C)(C)CCC4(C)C)c3ccc4c(c3)C(C)(C)CCC4(C)C)ccc2B2c3ccc4c(c3N(c3cc5c(cc3C)C(C)(C)CCC5(C)C)c3cc(-c5ccccc5)cc1c32)C(C)(C)c1ccc(C(C)(C)C)cc1-4 ; Cc1cc2c(cc1N(c1ccc3c(c1)N(c1ccccc1C)c1cc(C4CCCCC4)cc4c1B3c1cc3c(cc1N4c1cc4c(cc1C)C(C)(C)CCC4(C)C)sc1ccc(C(C)(C)C)cc13)c1ccc3c(c1)C(C)(C)CCC3(C)C)C(C)(C)CCC2(C)C]

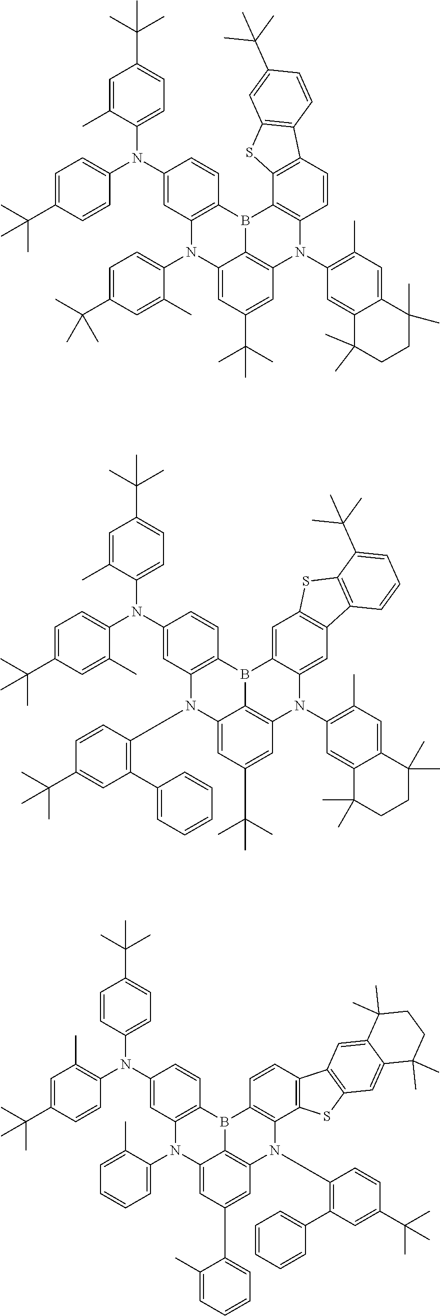

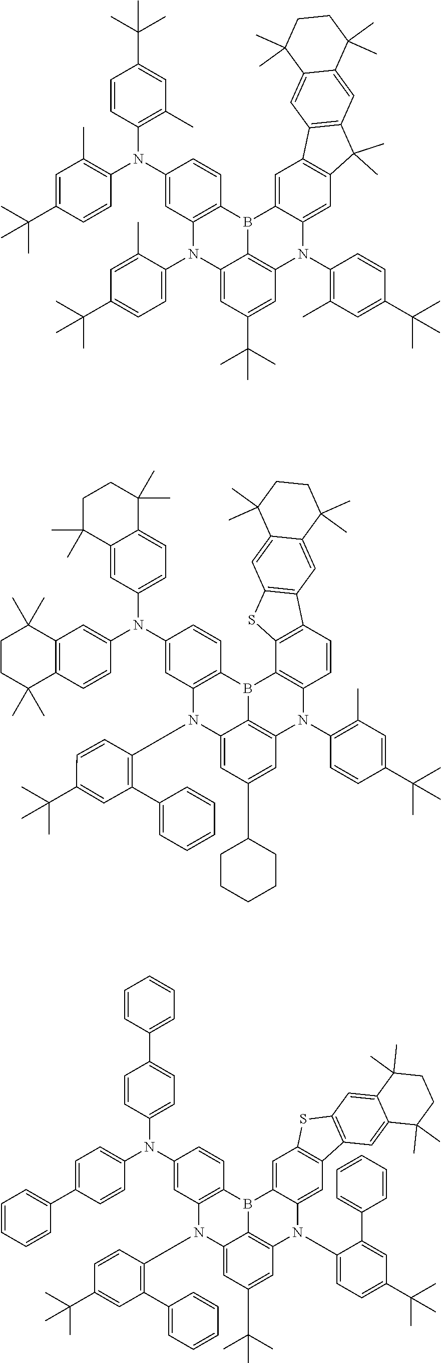

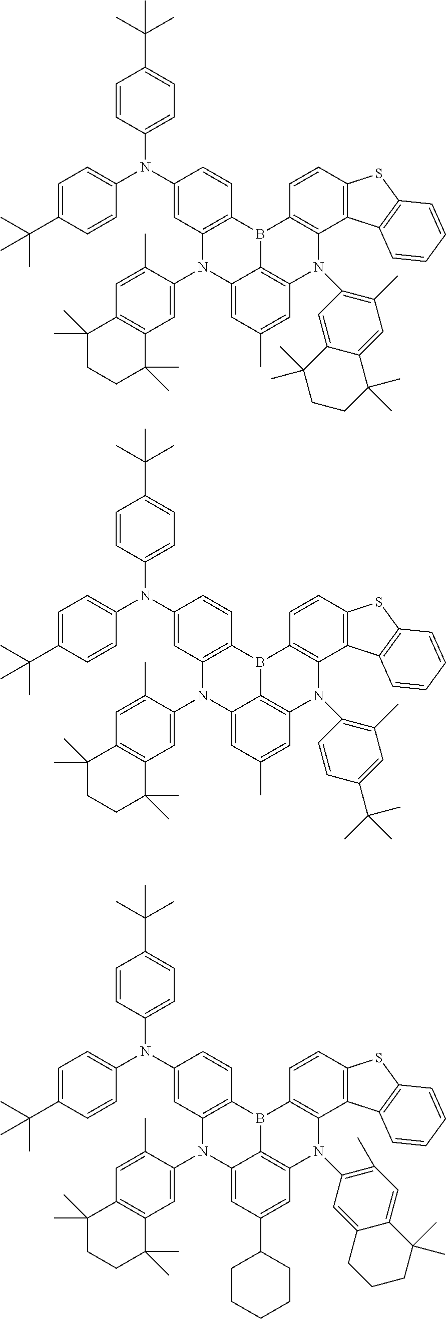

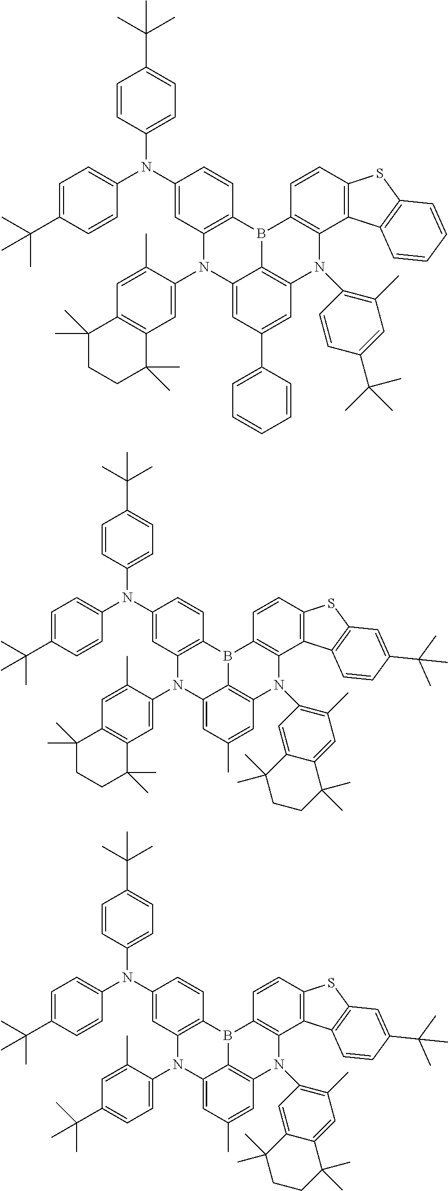

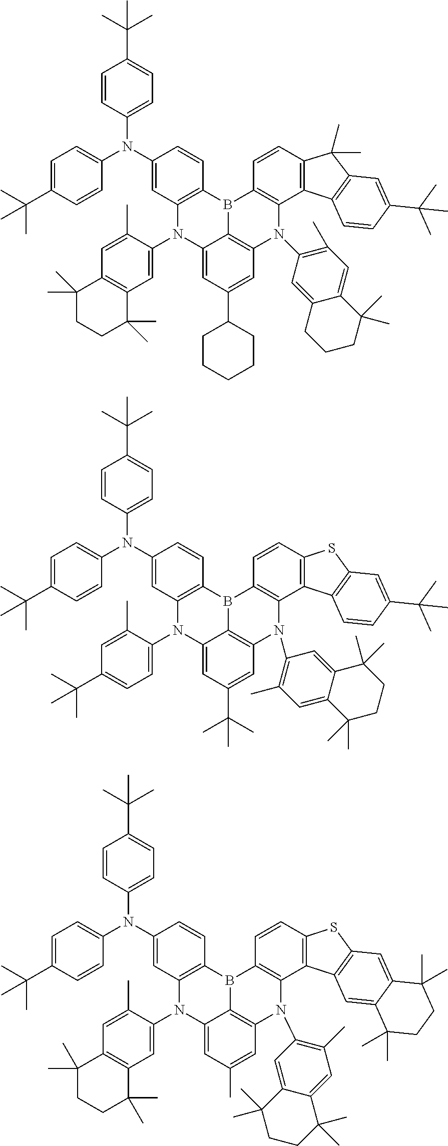

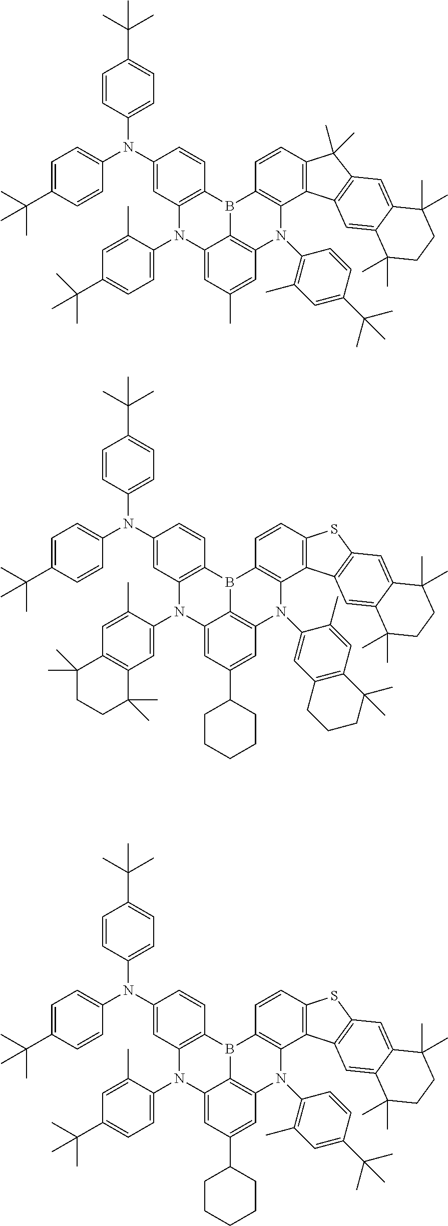

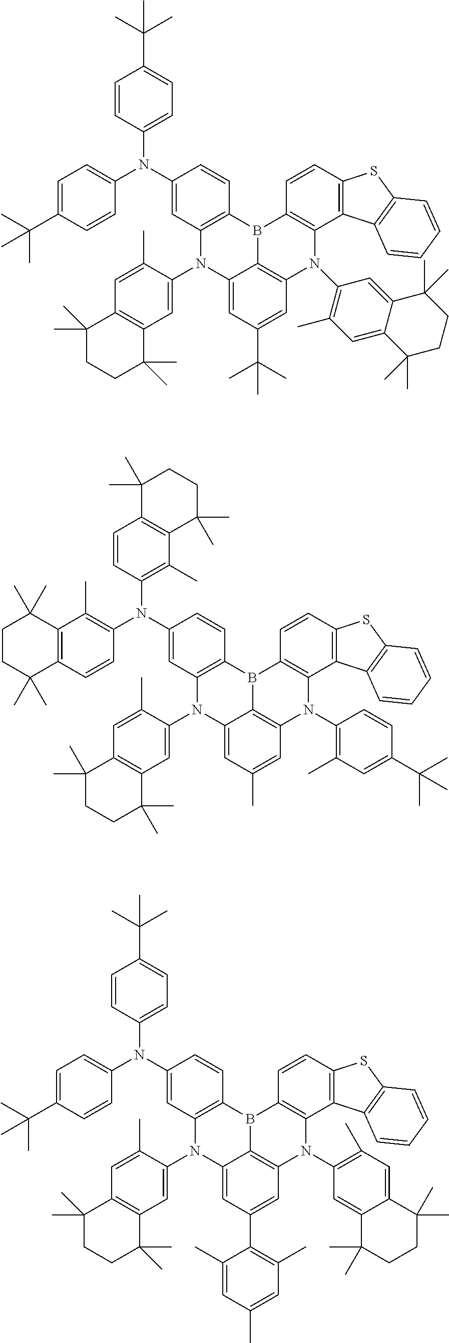

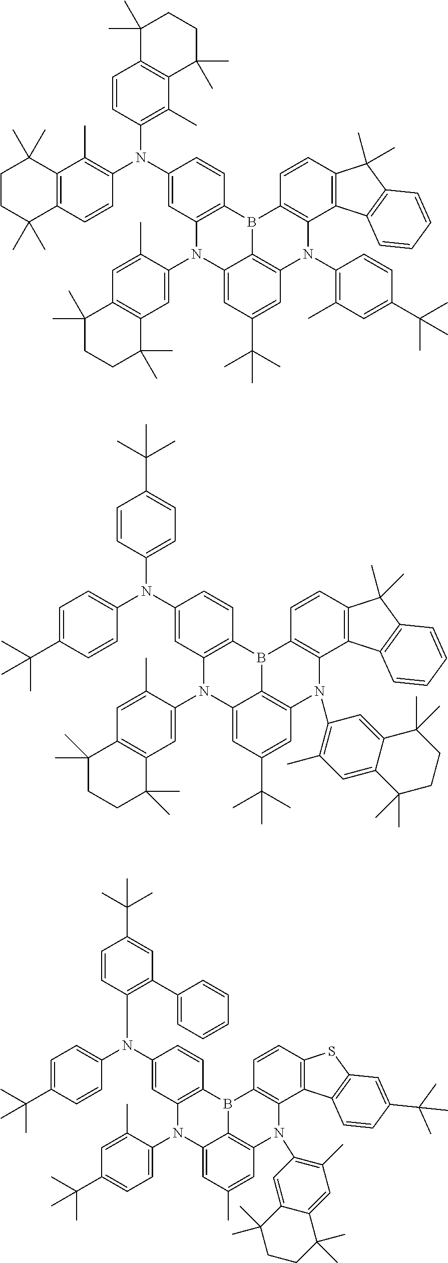

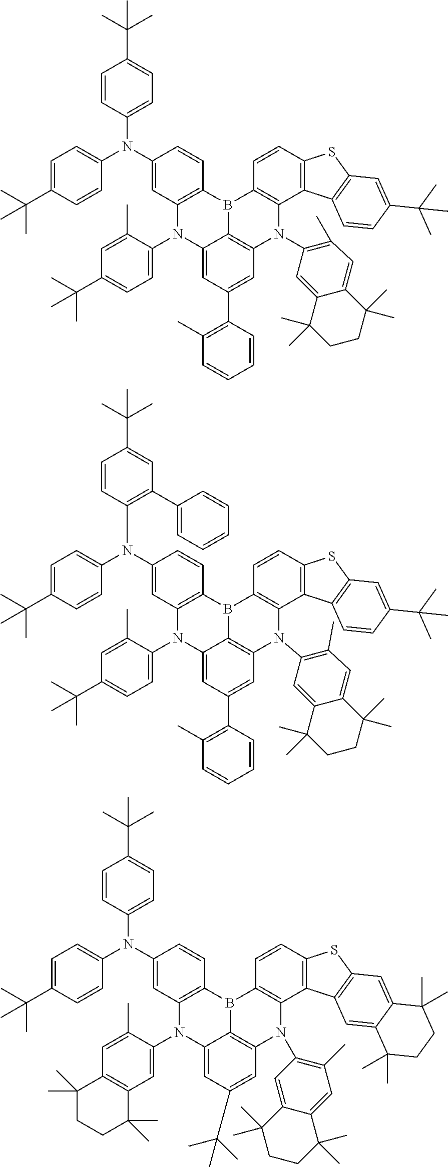

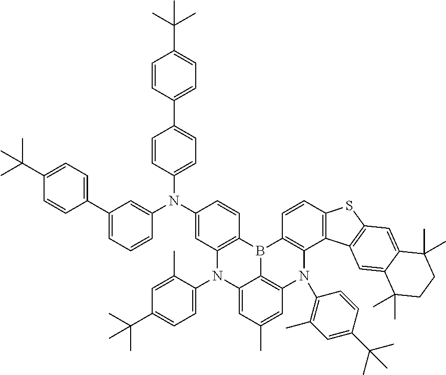 [SMILES: Cc1cc2c3c(c1)N(c1ccc(C(C)(C)C)cc1C)c1c(ccc4sc5cc6c(cc5c14)C(C)(C)CCC6(C)C)B3c1ccc(N(c3ccc(-c4ccc(C(C)(C)C)cc4)cc3)c3cccc(-c4ccc(C(C)(C)C)cc4)c3)cc1N2c1ccc(C(C)(C)C)cc1C]

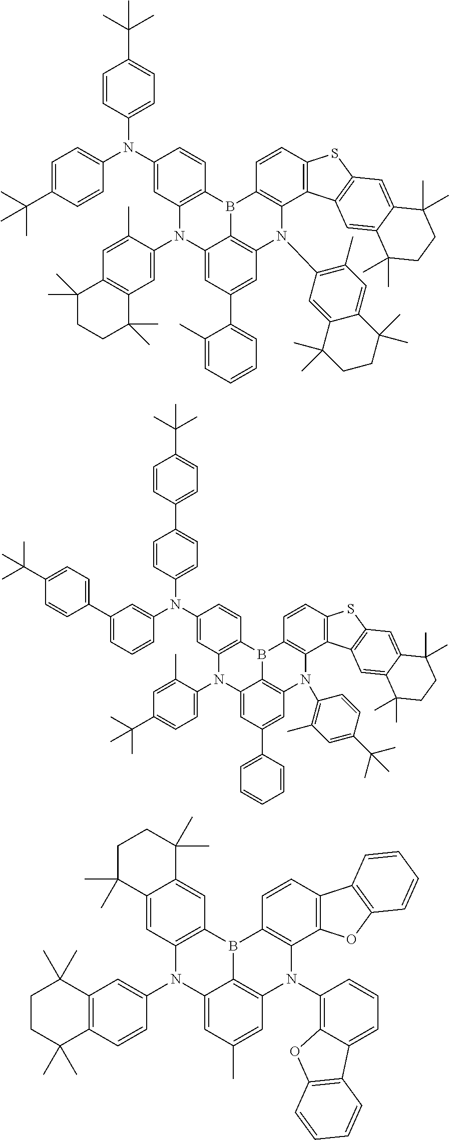

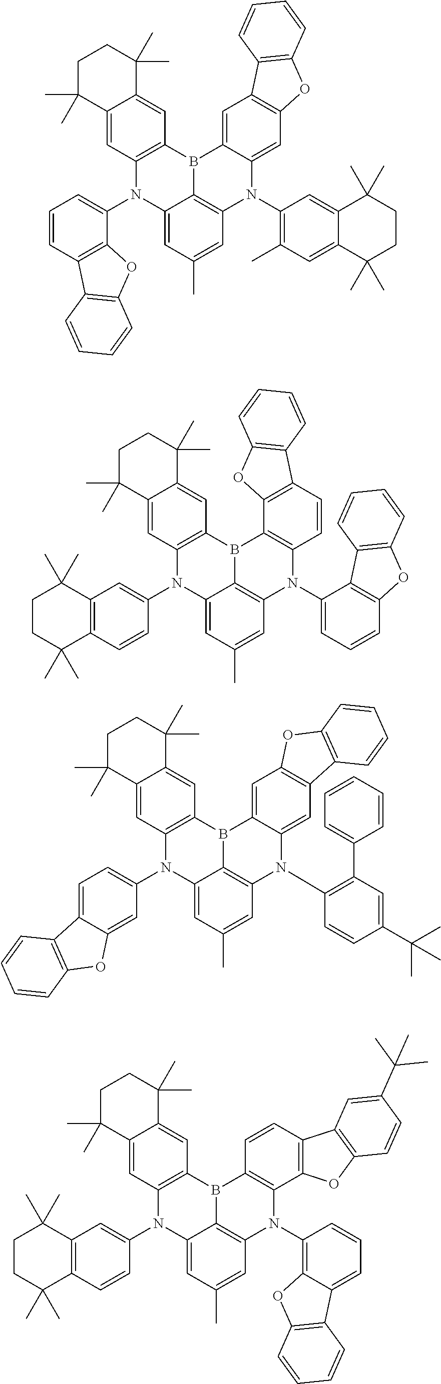 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)oc1ccccc13)C(C)(C)CCC4(C)C ; Cc1cc2c3c(c1)N(c1cccc4oc5ccccc5c14)c1ccc4c(oc5ccccc54)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1ccccc14 ; Cc1cc2c3c(c1)N(c1cccc4c1oc1ccccc14)c1c(ccc4c1oc1ccc(C(C)(C)C)cc14)B3c1cc3c(cc1N2c1ccc2c(c1)C(C)(C)CCC2(C)C)C(C)(C)CCC3(C)C]

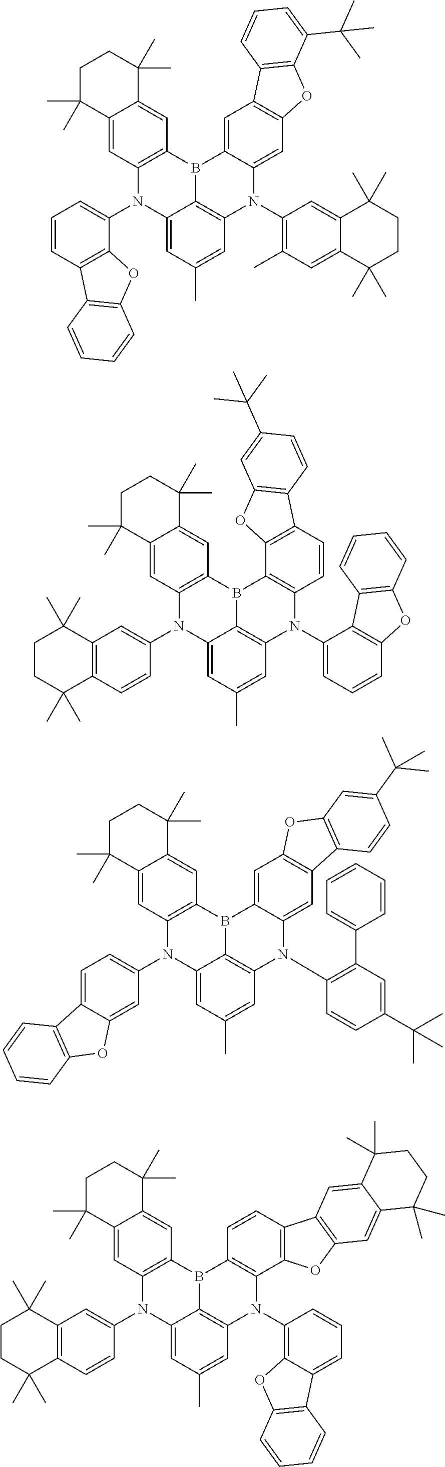

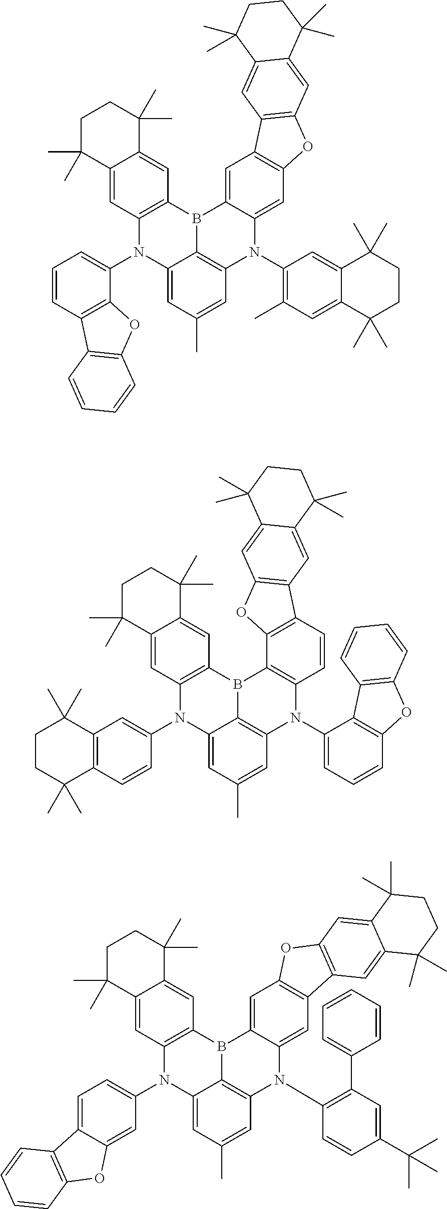 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)oc1cc2c(cc13)C(C)(C)CCC2(C)C)C(C)(C)CCC4(C)C ; Cc1cc2c3c(c1)N(c1cccc4oc5ccccc5c14)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1cc2c(cc14)C(C)(C)CCC2(C)C]

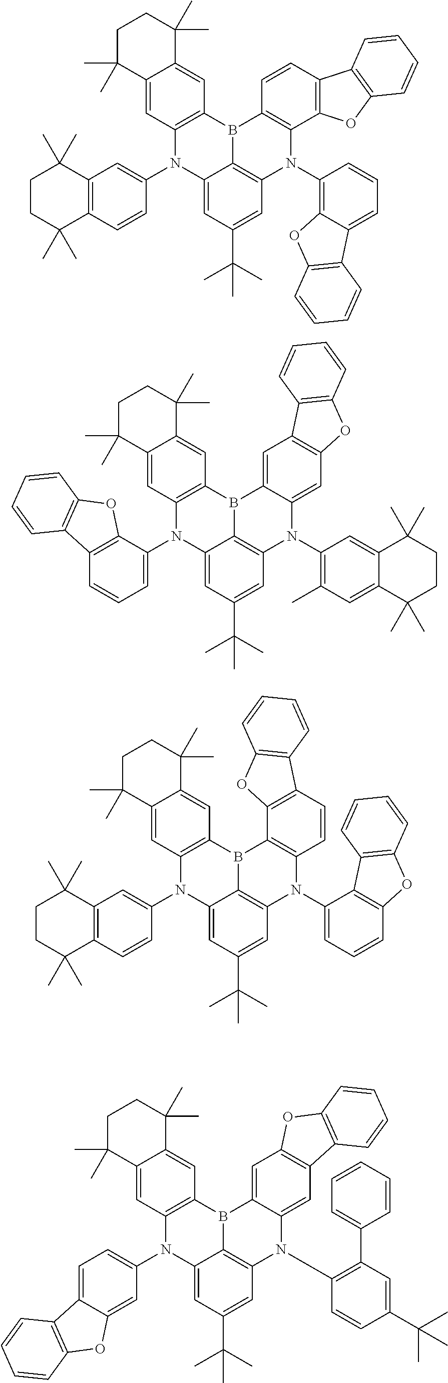

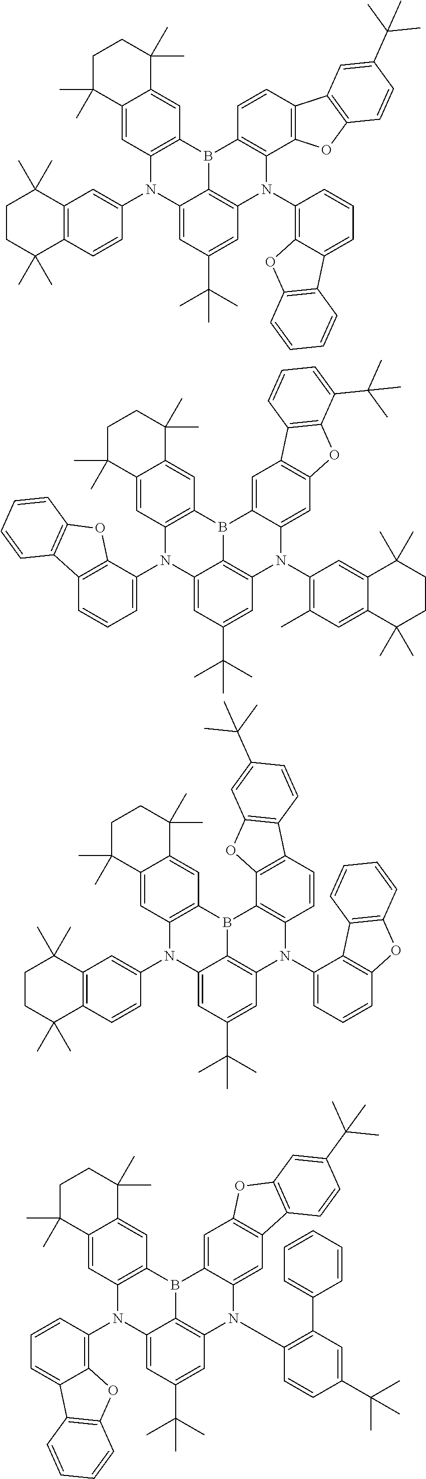

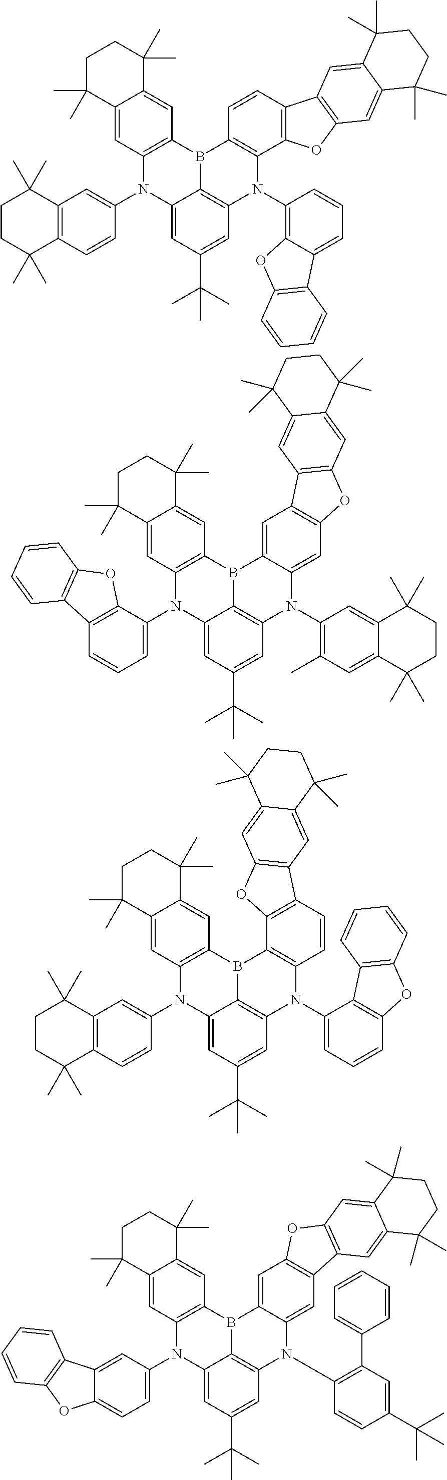

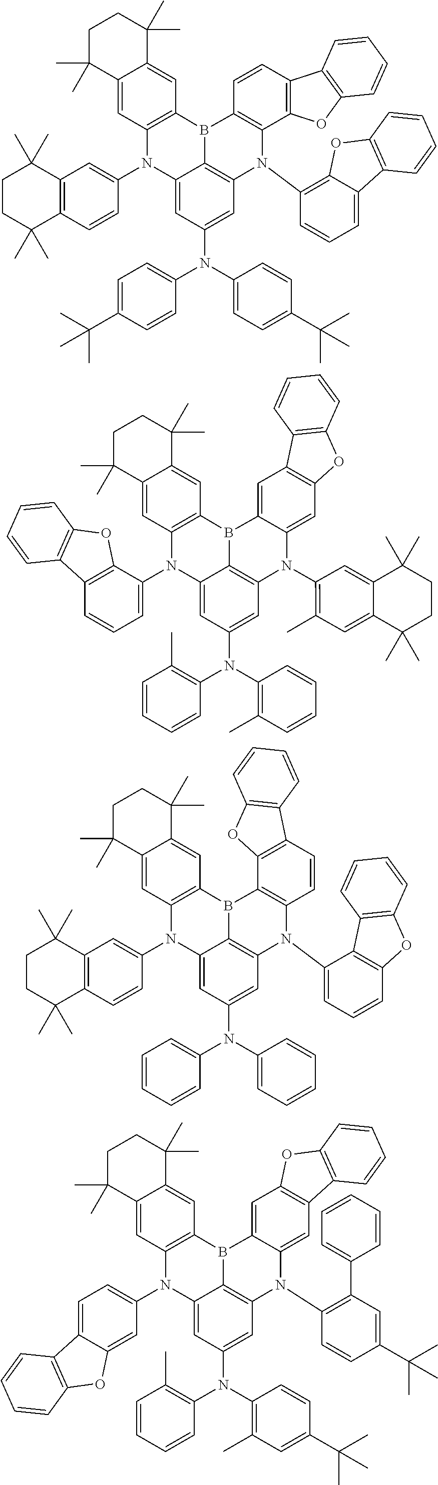

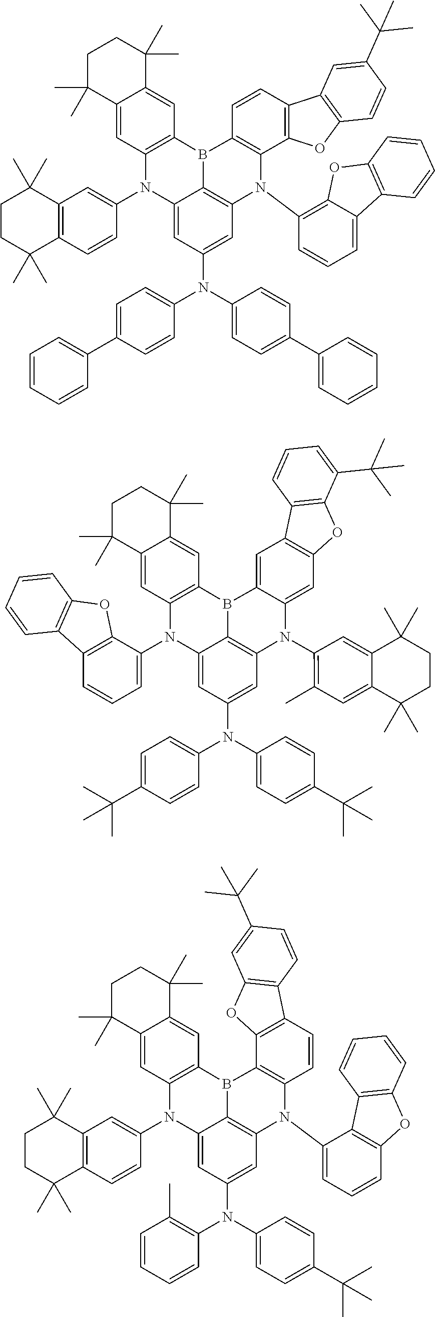 [SMILES: CC(C)(C)c1ccc2oc3c4c(ccc3c2c1)B1c2cc3c(cc2N(c2ccc5c(c2)C(C)(C)CCC5(C)C)c2cc(N(c5ccc(-c6ccccc6)cc5)c5ccc(-c6ccccc6)cc5)cc(c21)N4c1cccc2c1oc1ccccc12)C(C)(C)CCC3(C)C ; Cc1cc2c(cc1N1c3cc4oc5c(C(C)(C)C)cccc5c4cc3B3c4cc5c(cc4N(c4cccc6c4oc4ccccc46)c4cc(N(c6ccc(C(C)(C)C)cc6)c6ccc(C(C)(C)C)cc6)cc1c43)C(C)(C)CCC5(C)C)C(C)(C)CCC2(C)C ; Cc1ccccc1N(c1ccc(C(C)(C)C)cc1)c1cc2c3c(c1)N(c1cccc4oc5ccccc5c14)c1ccc4c(oc5cc(C(C)(C)C)ccc54)c1B3c1cc3c(cc1N2c1ccc2c(c1)C(C)(C)CCC2(C)C)C(C)(C)CCC3(C)C]

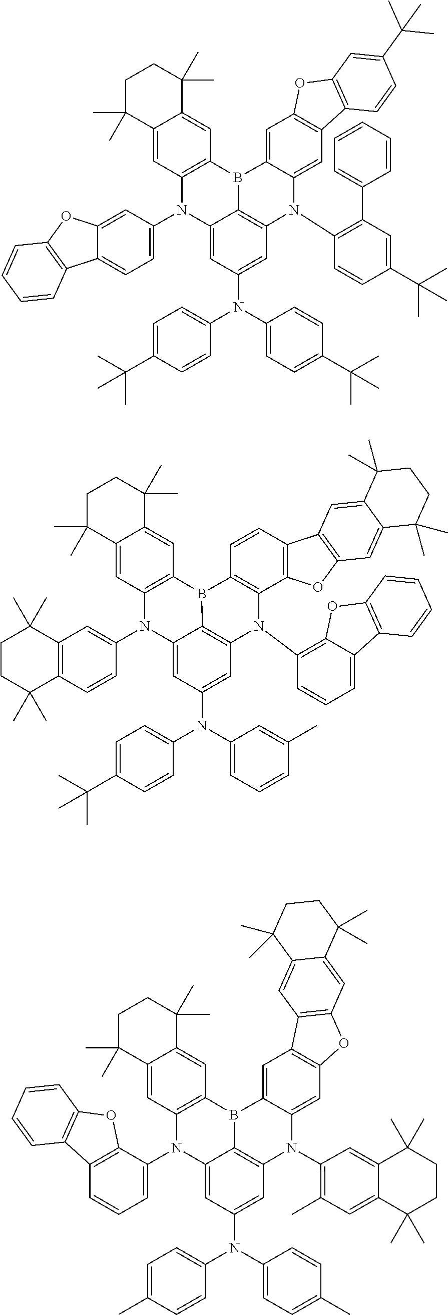

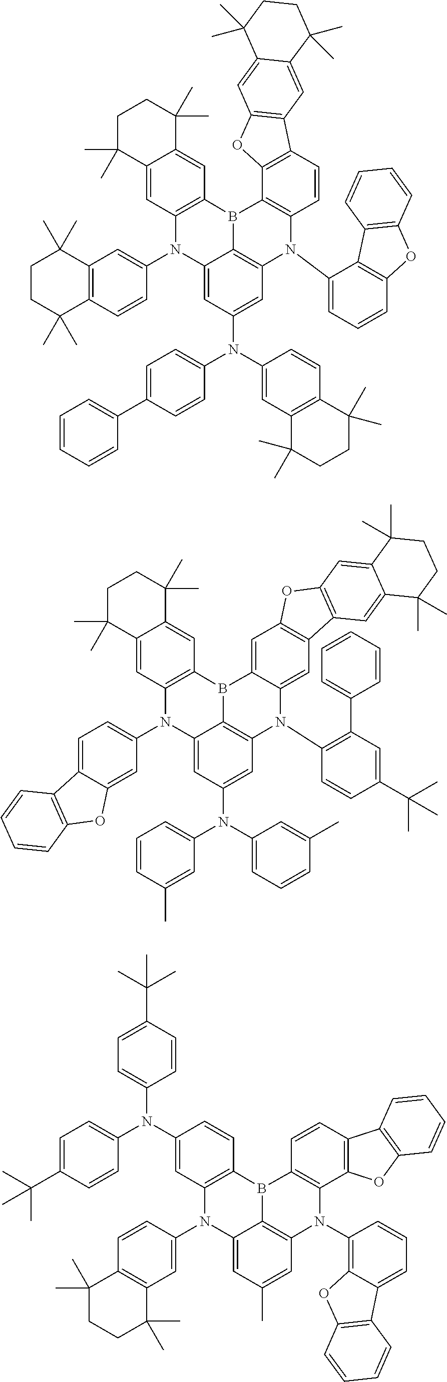

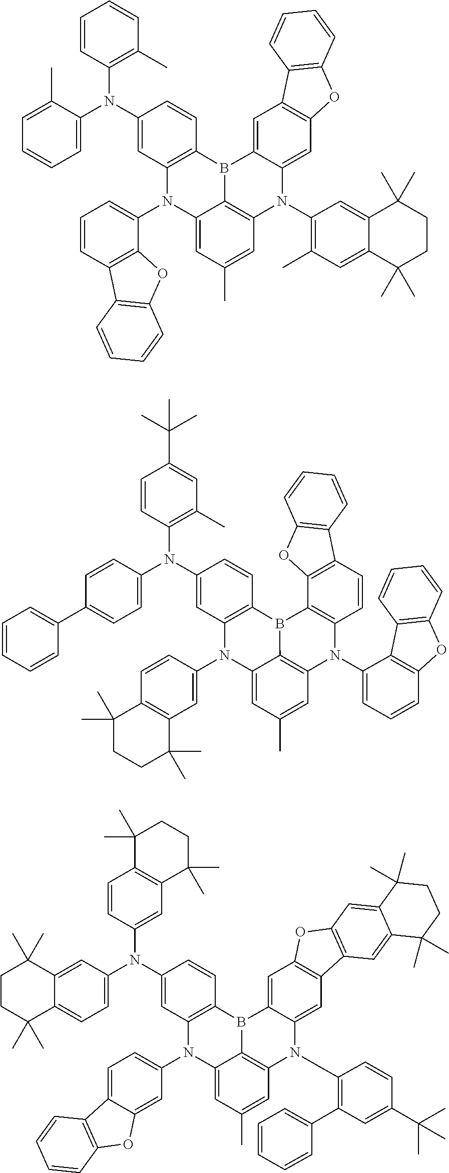 [SMILES: Cc1cc2c3c(c1)N(c1cccc4c1oc1ccccc14)c1cc(N(c4ccccc4C)c4ccccc4C)ccc1B3c1cc3c(cc1N2c1cc2c(cc1C)C(C)(C)CCC2(C)C)oc1ccccc13 ; Cc1cc2c3c(c1)N(c1cccc4oc5ccccc5c14)c1ccc4c(oc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)oc1cc2c(cc14)C(C)(C)CCC2(C)C]

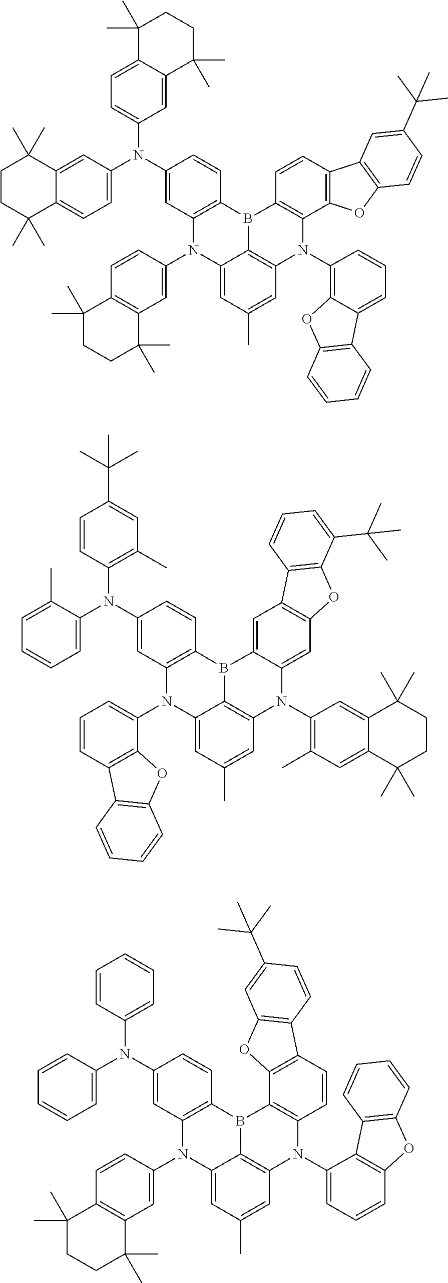

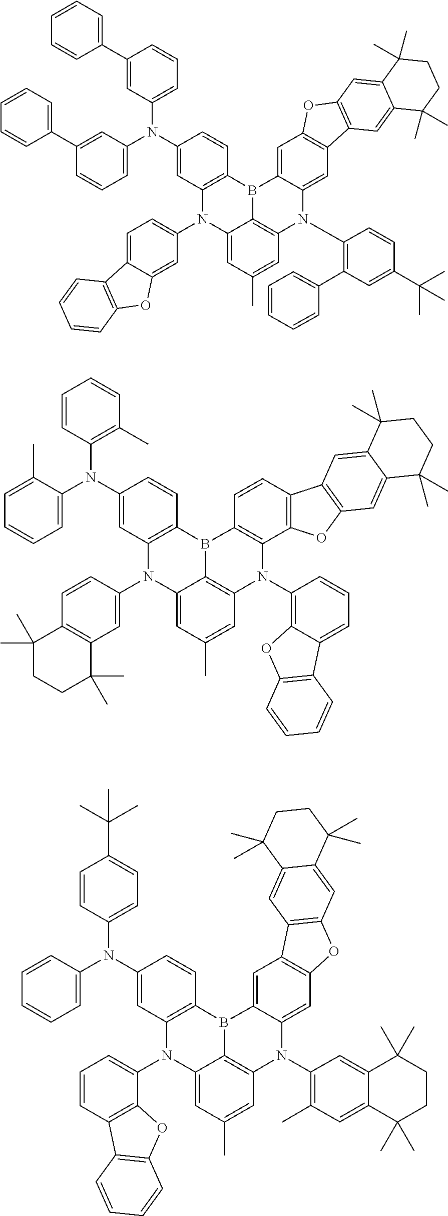

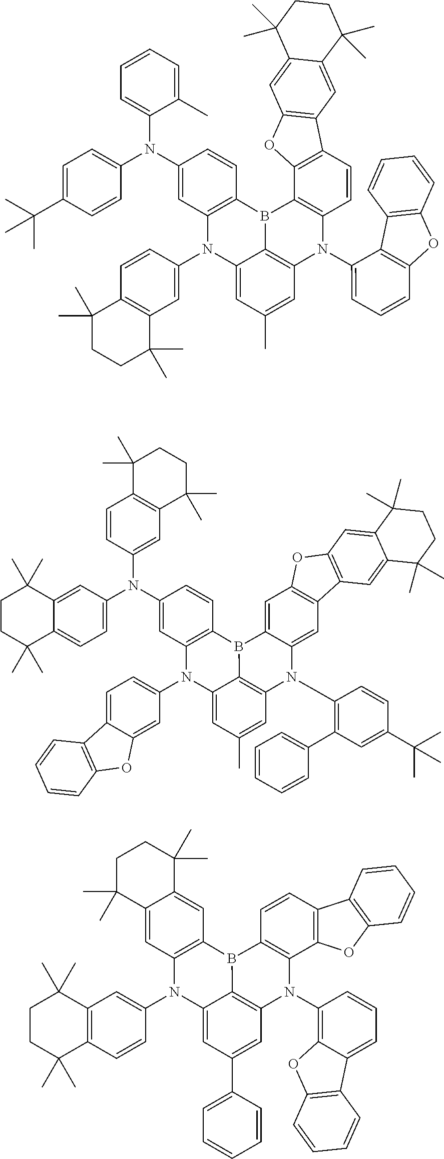 [SMILES: Cc1cc2c3c(c1)N(c1cccc4oc5ccccc5c14)c1ccc4c(oc5cc6c(cc54)C(C)(C)CCC6(C)C)c1B3c1ccc(N(c3ccc(C(C)(C)C)cc3)c3ccccc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)oc1cc2c(cc14)C(C)(C)CCC2(C)C ; CC1(C)CCC(C)(C)c2cc(N3c4cc5c(cc4B4c6ccc7c(oc8ccccc87)c6N(c6cccc7c6oc6ccccc67)c6cc(-c7ccccc7)cc3c64)C(C)(C)CCC5(C)C)ccc21]

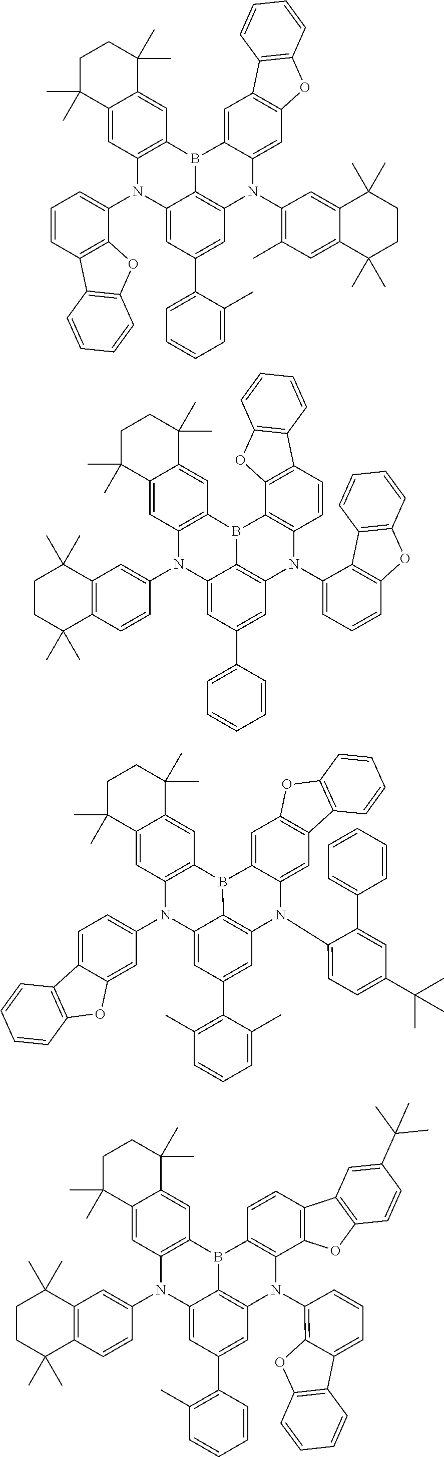

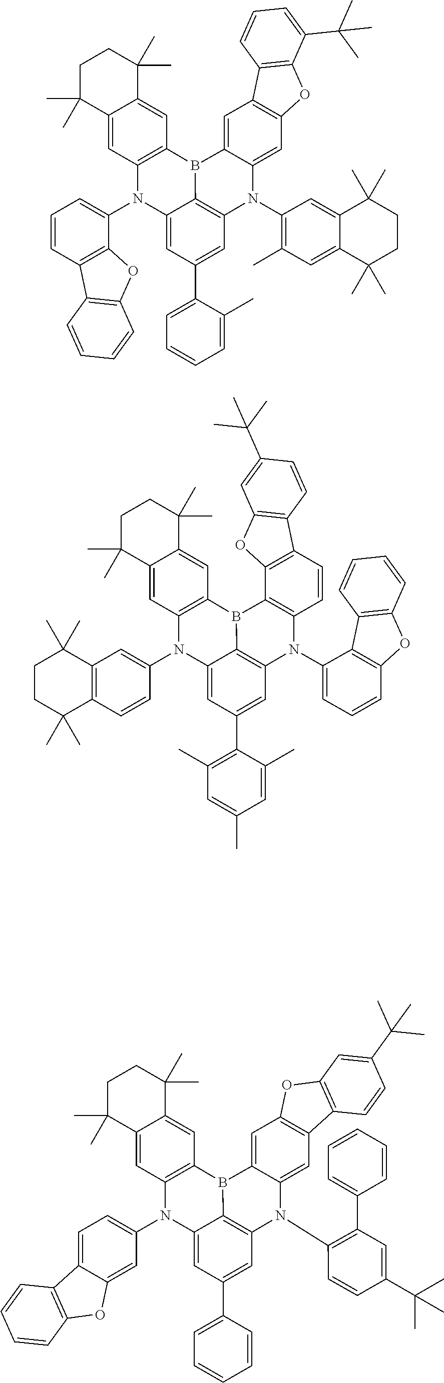 [SMILES: Cc1ccccc1-c1cc2c3c(c1)N(c1cccc4c1oc1ccccc14)c1cc4c(cc1B3c1cc3c(cc1N2c1cc2c(cc1C)C(C)(C)CCC2(C)C)oc1c(C(C)(C)C)cccc13)C(C)(C)CCC4(C)C ; Cc1cc(C)c(-c2cc3c4c(c2)N(c2cccc5oc6ccccc6c25)c2ccc5c(oc6cc(C(C)(C)C)ccc65)c2B4c2cc4c(cc2N3c2ccc3c(c2)C(C)(C)CCC3(C)C)C(C)(C)CCC4(C)C)c(C)c1 ; CC(C)(C)c1ccc(N2c3cc4c(cc3B3c5cc6c(cc5N(c5ccc7c(c5)oc5ccccc57)c5cc(-c7ccccc7)cc2c53)C(C)(C)CCC6(C)C)oc2cc(C(C)(C)C)ccc24)c(-c2ccccc2)c1]

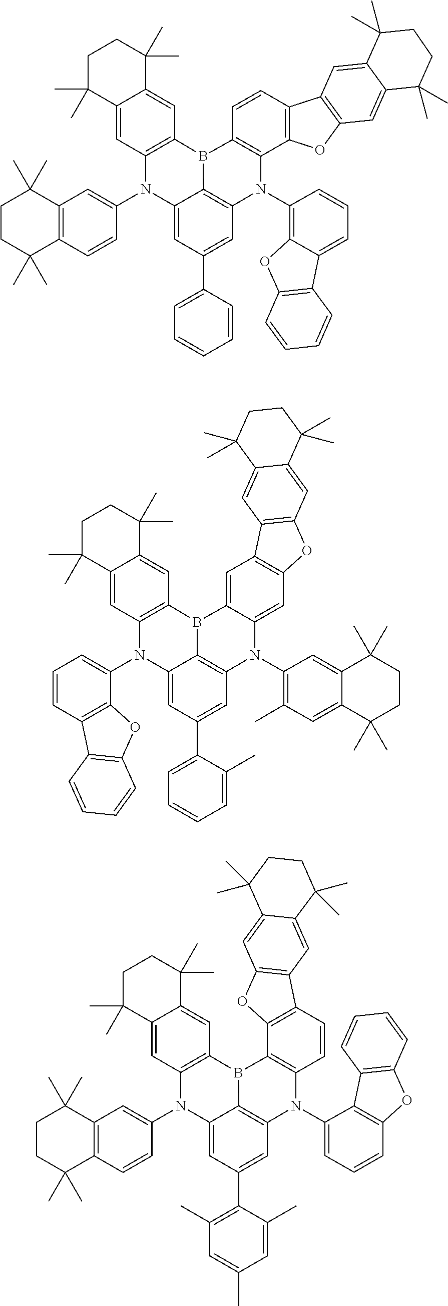

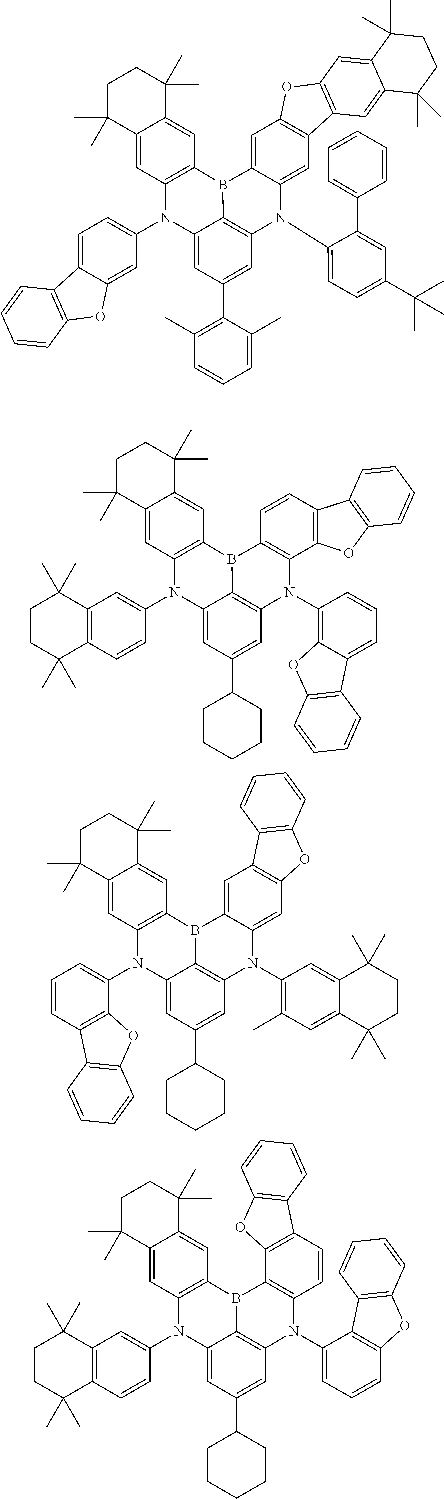

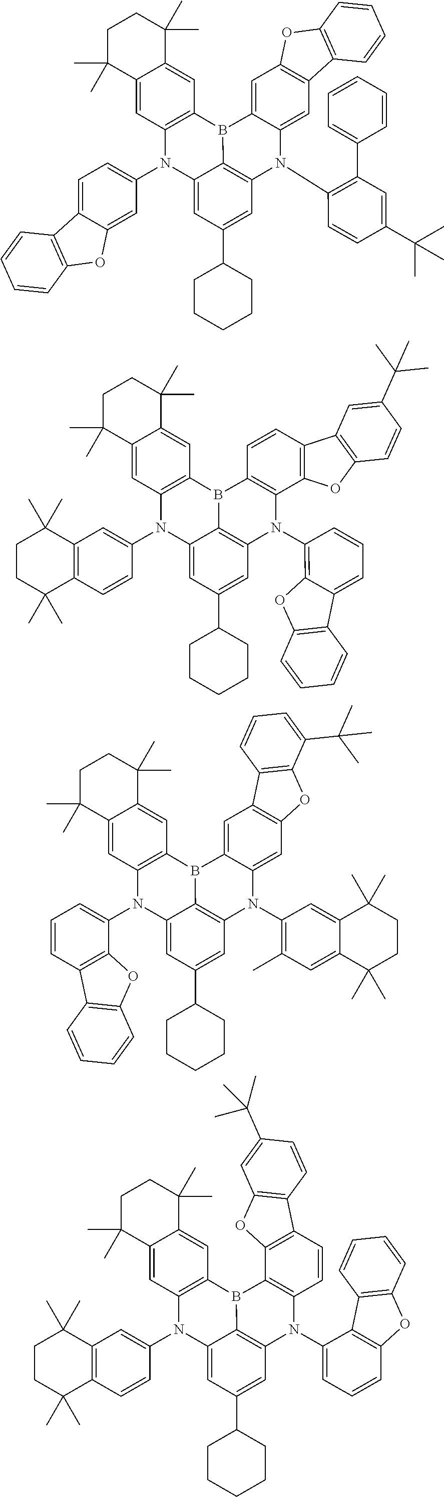

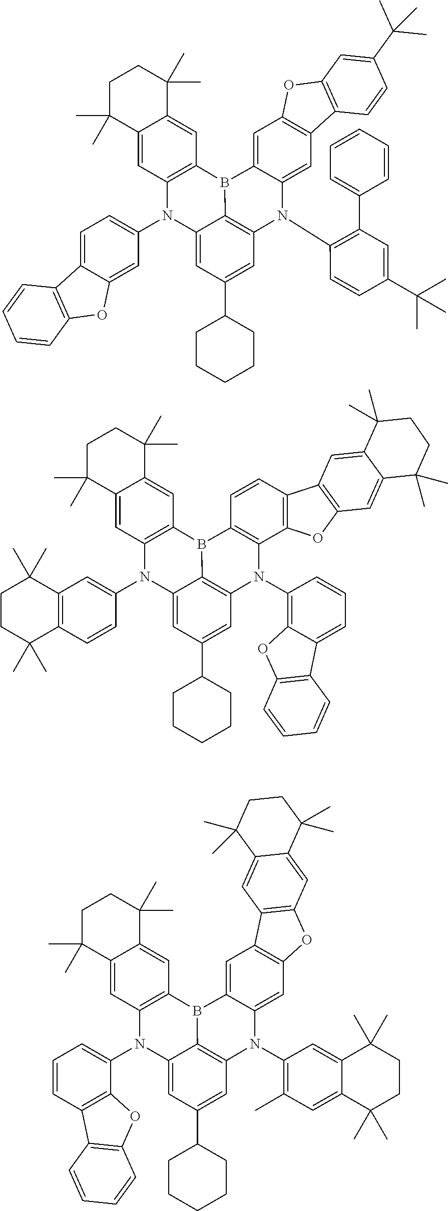

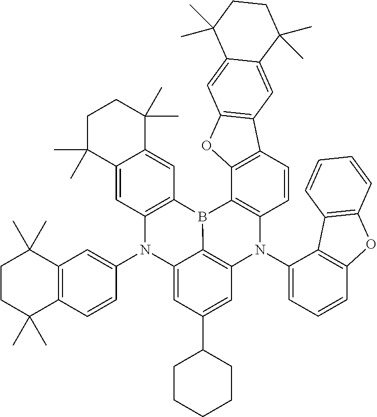 [SMILES: CC1(C)CCC(C)(C)c2cc(N3c4cc5c(cc4B4c6c3cc(C3CCCCC3)cc6N(c3cccc6oc7ccccc7c36)c3ccc6c(oc7cc8c(cc76)C(C)(C)CCC8(C)C)c34)C(C)(C)CCC5(C)C)ccc21]

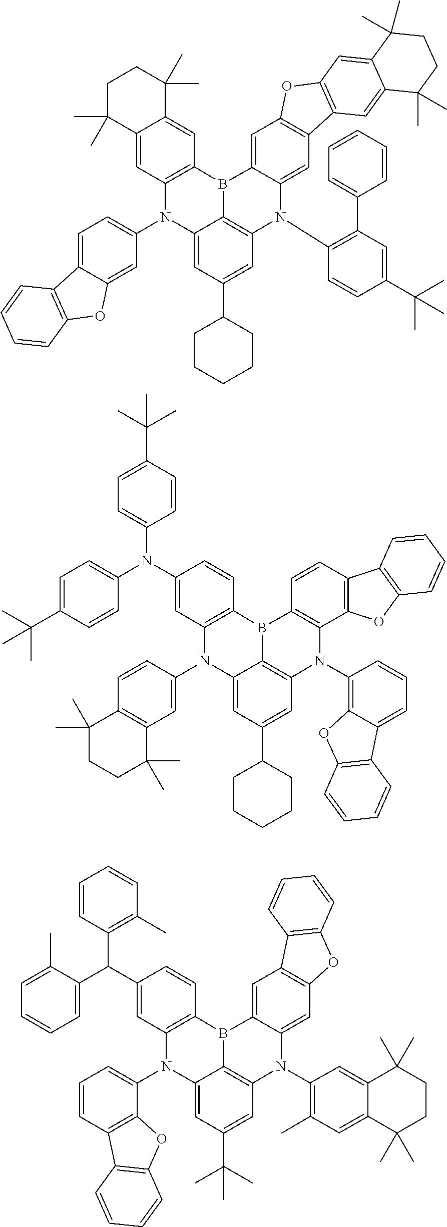

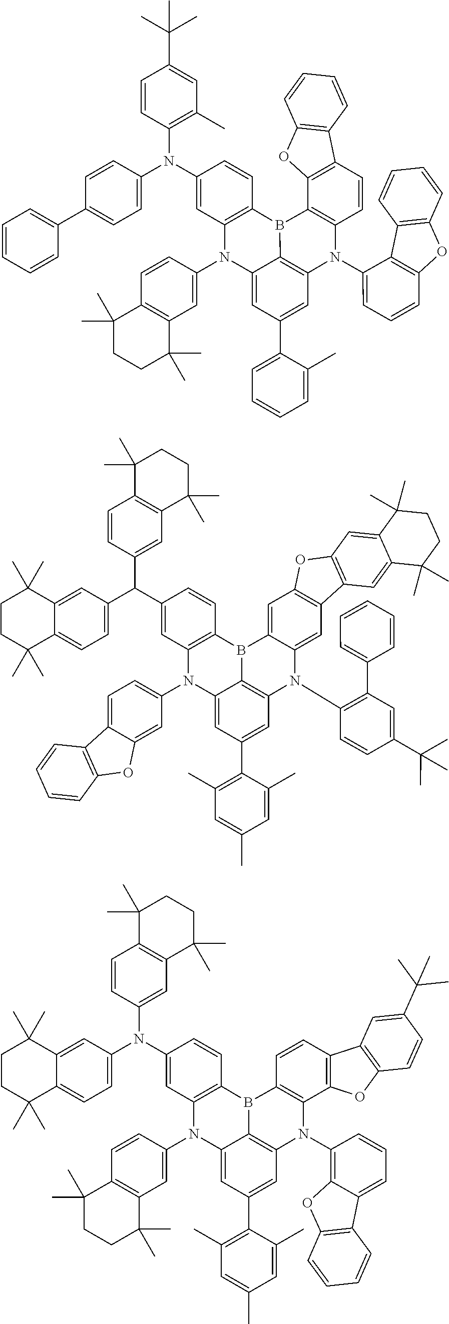

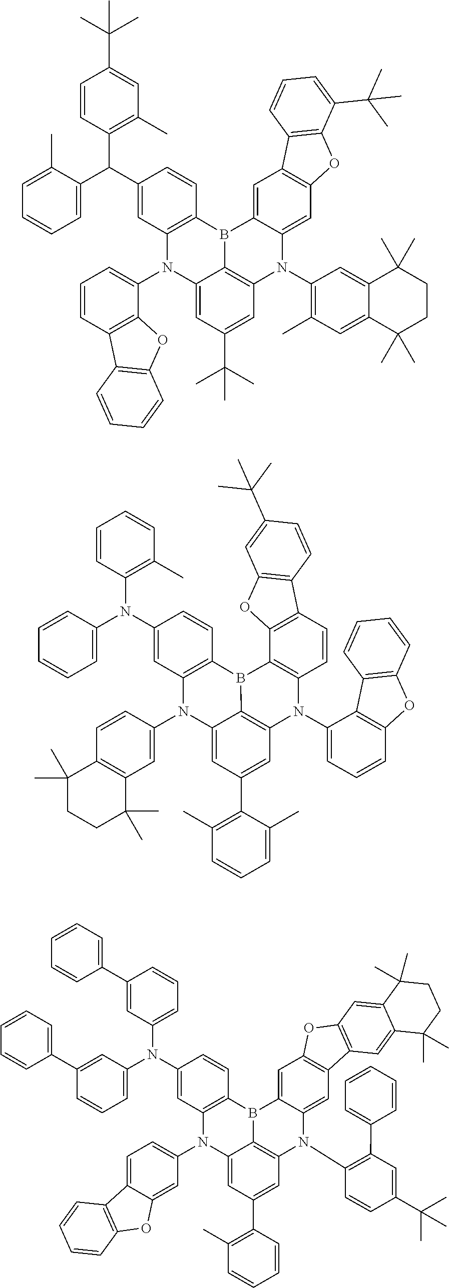 [SMILES: Cc1ccccc1C(c1ccc2c(c1)N(c1cccc3c1oc1ccccc13)c1cc(C(C)(C)C)cc3c1B2c1cc2c(cc1N3c1cc3c(cc1C)C(C)(C)CCC3(C)C)oc1c(C(C)(C)C)cccc12)c1ccc(C(C)(C)C)cc1C ; Cc1ccccc1N(c1ccccc1)c1ccc2c(c1)N(c1ccc3c(c1)C(C)(C)CCC3(C)C)c1cc(-c3c(C)cccc3C)cc3c1B2c1c(ccc2c1oc1cc(C(C)(C)C)ccc12)N3c1cccc2oc3ccccc3c12 ; Cc1ccccc1-c1cc2c3c(c1)N(c1ccc(C(C)(C)C)cc1-c1ccccc1)c1cc4c(cc1B3c1ccc(N(c3cccc(-c5ccccc5)c3)c3cccc(-c5ccccc5)c3)cc1N2c1ccc2c(c1)oc1ccccc12)oc1cc2c(cc14)C(C)(C)CCC2(C)C]

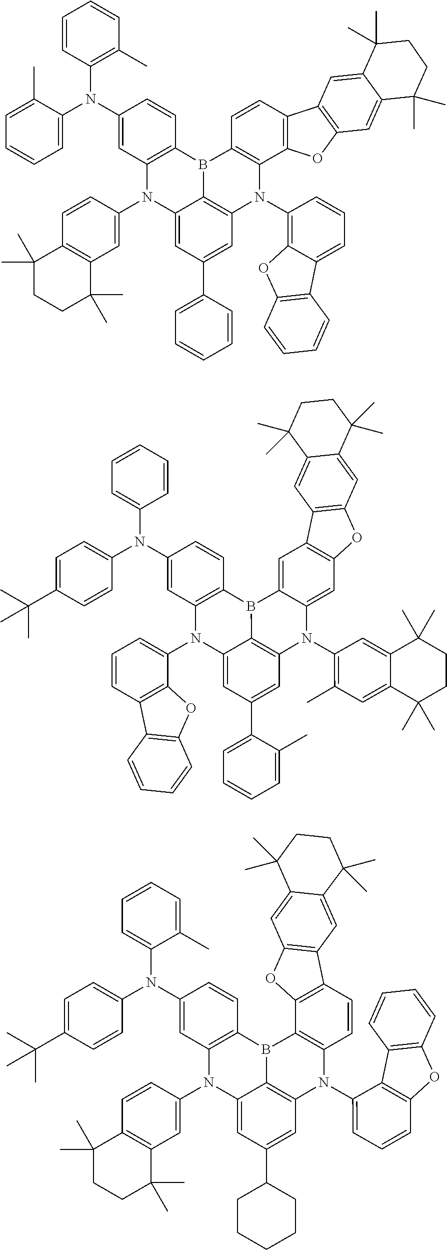

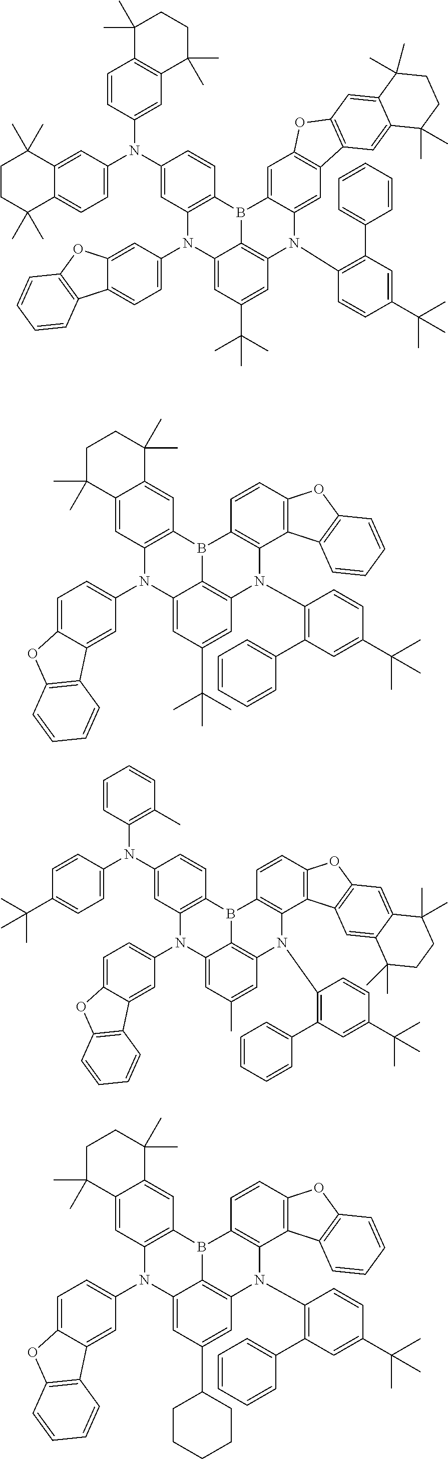

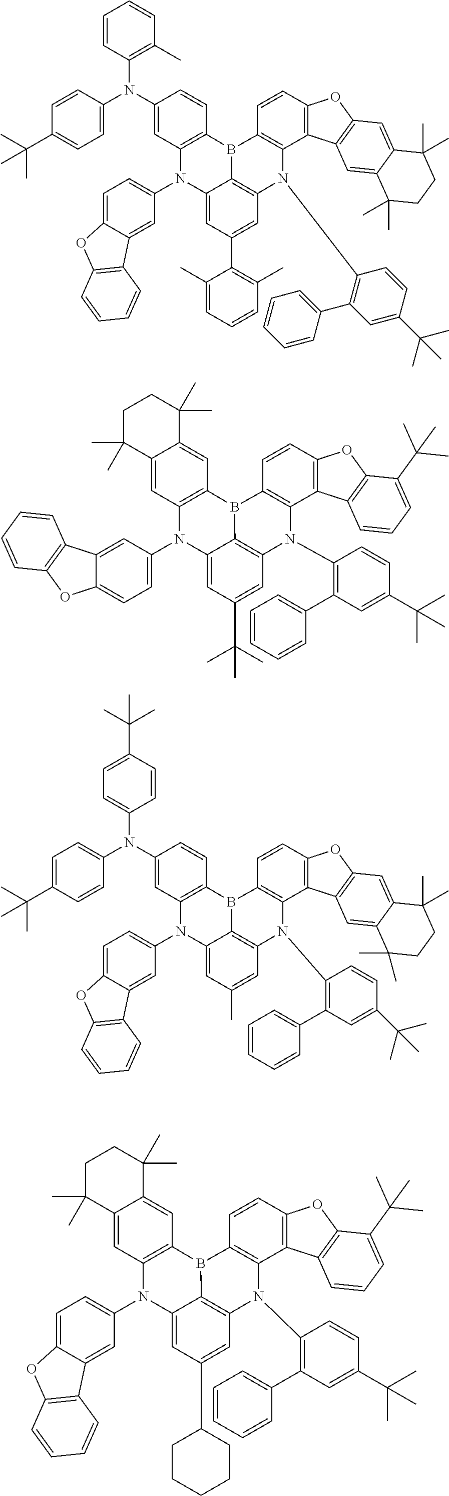

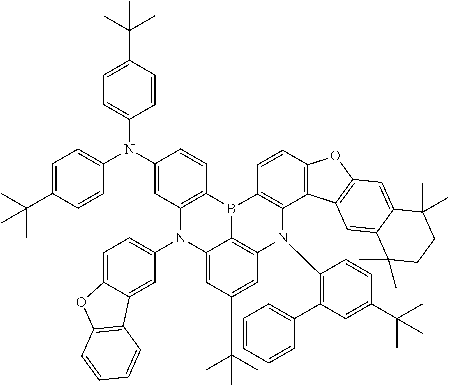 [SMILES: CC(C)(C)c1ccc(N(c2ccc(C(C)(C)C)cc2)c2ccc3c(c2)N(c2ccc4oc5ccccc5c4c2)c2cc(C(C)(C)C)cc4c2B3c2ccc3oc5cc6c(cc5c3c2N4c2ccc(C(C)(C)C)cc2-c2ccccc2)C(C)(C)CCC6(C)C)cc1]

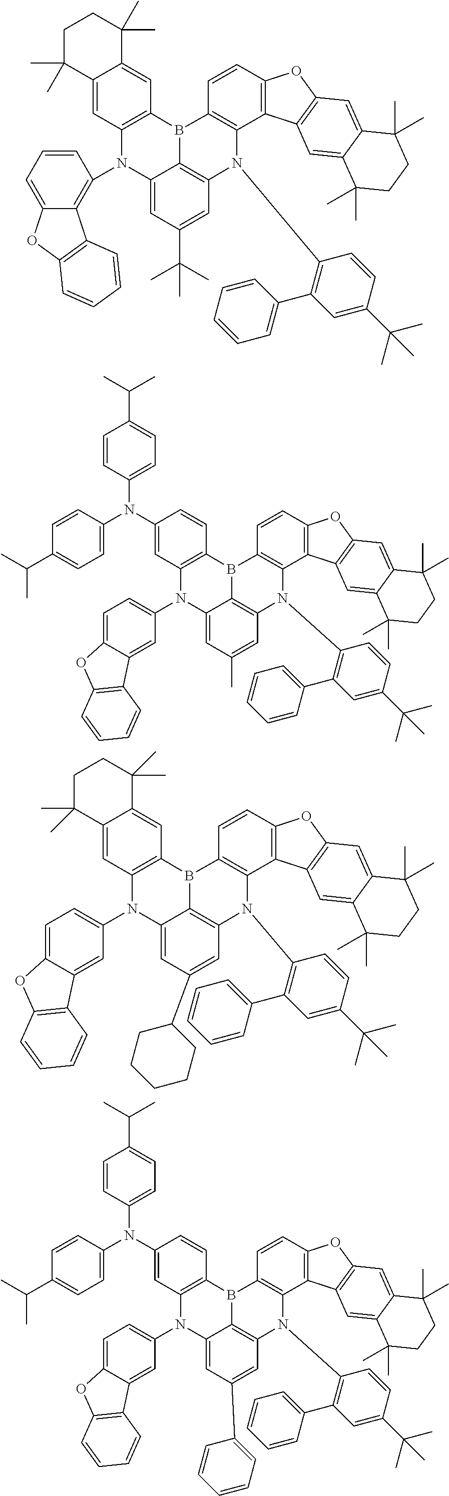

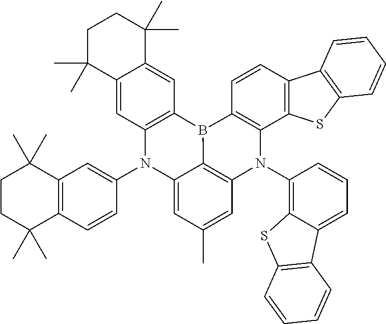 [SMILES: Cc1cc2c3c(c1)N(c1cccc4c1sc1ccccc14)c1c(ccc4c1sc1ccccc14)B3c1cc3c(cc1N2c1ccc2c(c1)C(C)(C)CCC2(C)C)C(C)(C)CCC3(C)C]

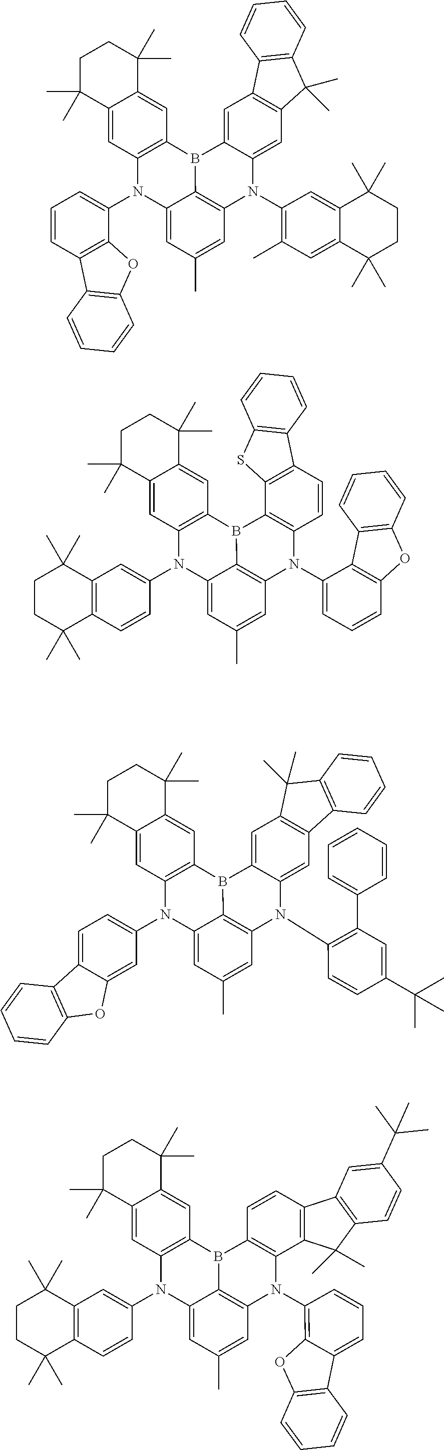 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)C(C)(C)c1ccccc1-3)C(C)(C)CCC4(C)C ; Cc1cc2c3c(c1)N(c1cccc4oc5ccccc5c14)c1ccc4c(sc5ccccc54)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)C(C)(C)c1ccccc1-4 ; Cc1cc2c3c(c1)N(c1cccc4c1oc1ccccc14)c1c(ccc4c1C(C)(C)c1ccc(C(C)(C)C)cc1-4)B3c1cc3c(cc1N2c1ccc2c(c1)C(C)(C)CCC2(C)C)C(C)(C)CCC3(C)C]

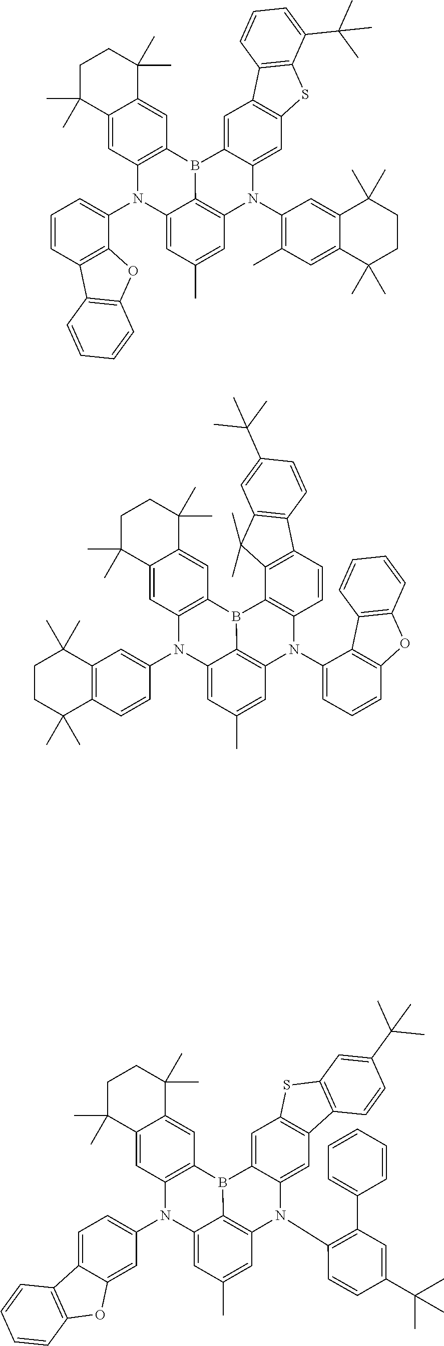 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)sc1c(C(C)(C)C)cccc13)C(C)(C)CCC4(C)C ; Cc1cc2c3c(c1)N(c1cccc4oc5ccccc5c14)c1ccc4c(c1B3c1cc3c(cc1N2c1ccc2c(c1)C(C)(C)CCC2(C)C)C(C)(C)CCC3(C)C)C(C)(C)c1cc(C(C)(C)C)ccc1-4 ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)sc1cc(C(C)(C)C)ccc14]

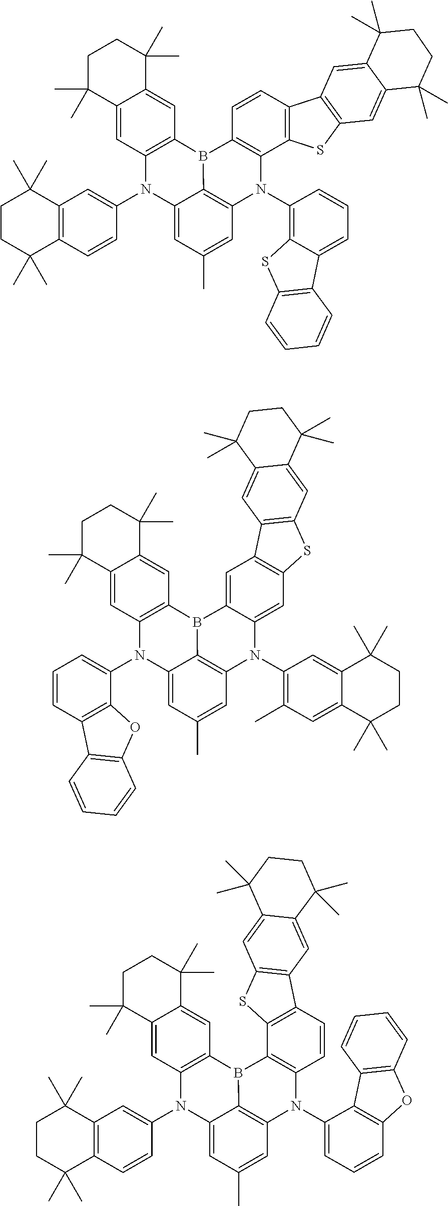

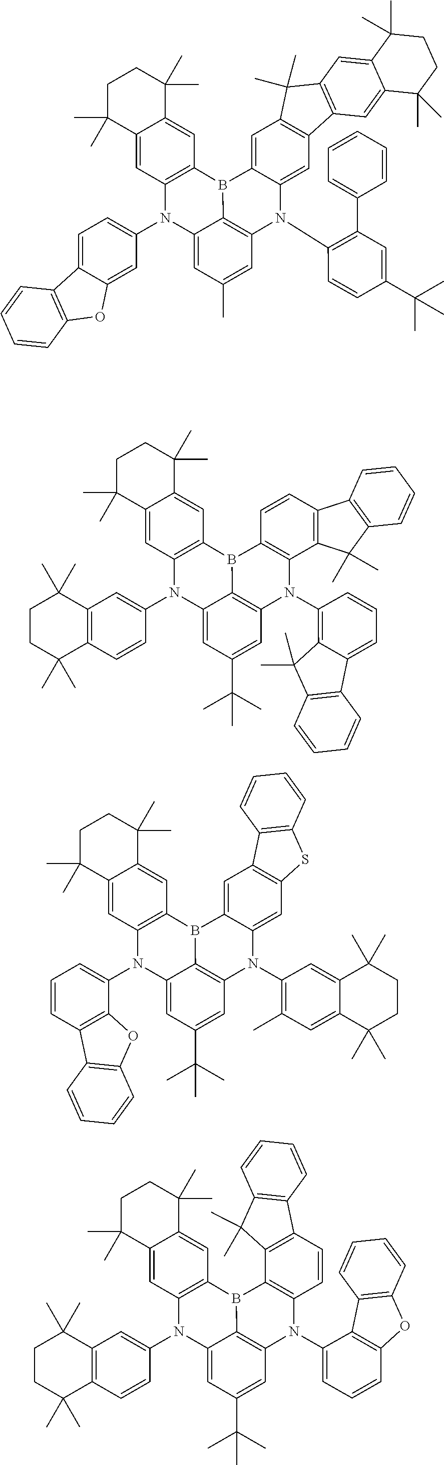

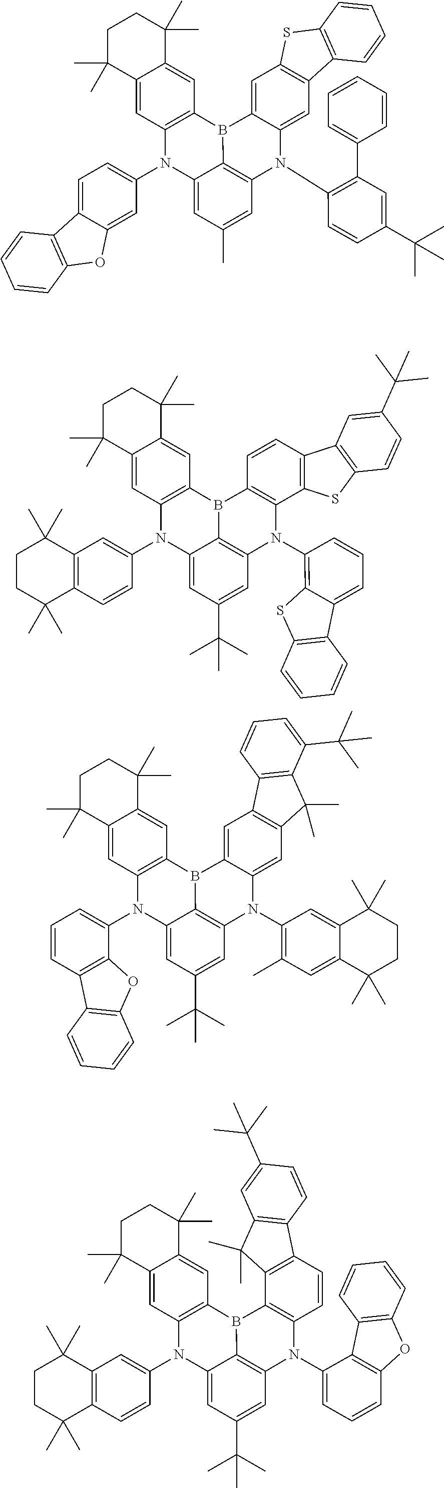

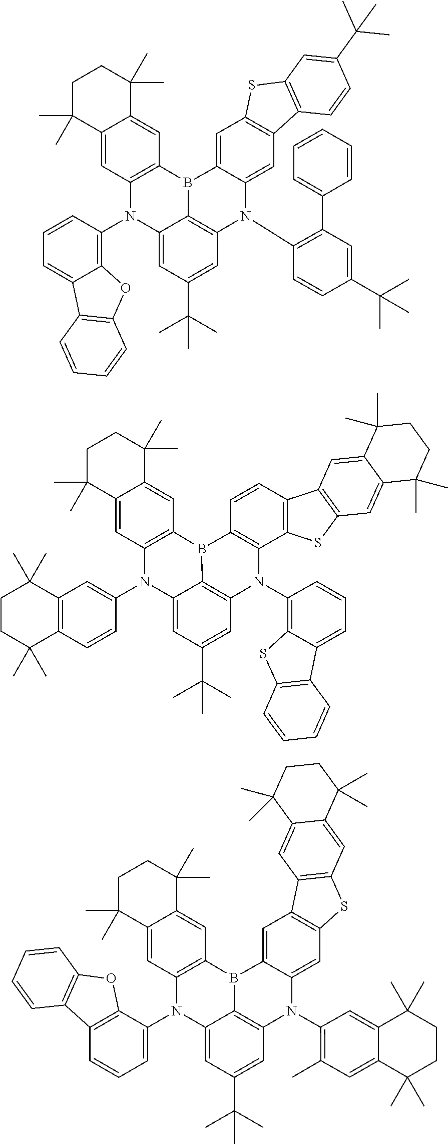

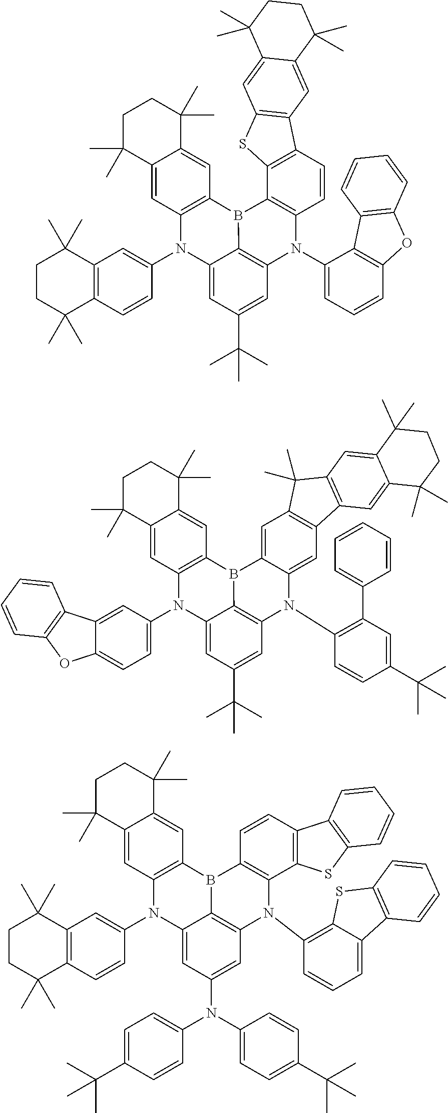 [SMILES: CC(C)(C)c1cc2c3c(c1)N(c1cccc4oc5ccccc5c14)c1ccc4c(sc5cc6c(cc54)C(C)(C)CCC6(C)C)c1B3c1cc3c(cc1N2c1ccc2c(c1)C(C)(C)CCC2(C)C)C(C)(C)CCC3(C)C ; CC(C)(C)c1ccc(N2c3cc4c(cc3B3c5cc6c(cc5N(c5ccc7oc8ccccc8c7c5)c5cc(C(C)(C)C)cc2c53)C(C)(C)CCC6(C)C)C(C)(C)c2cc3c(cc2-4)C(C)(C)CCC3(C)C)c(-c2ccccc2)c1 ; CC(C)(C)c1ccc(N(c2ccc(C(C)(C)C)cc2)c2cc3c4c(c2)N(c2cccc5c2sc2ccccc25)c2c(ccc5c2sc2ccccc25)B4c2cc4c(cc2N3c2ccc3c(c2)C(C)(C)CCC3(C)C)C(C)(C)CCC4(C)C)cc1]

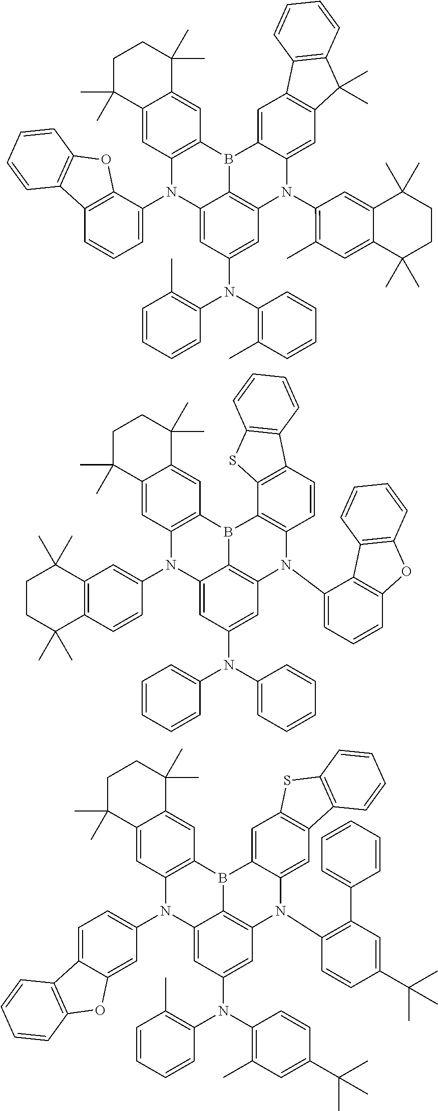

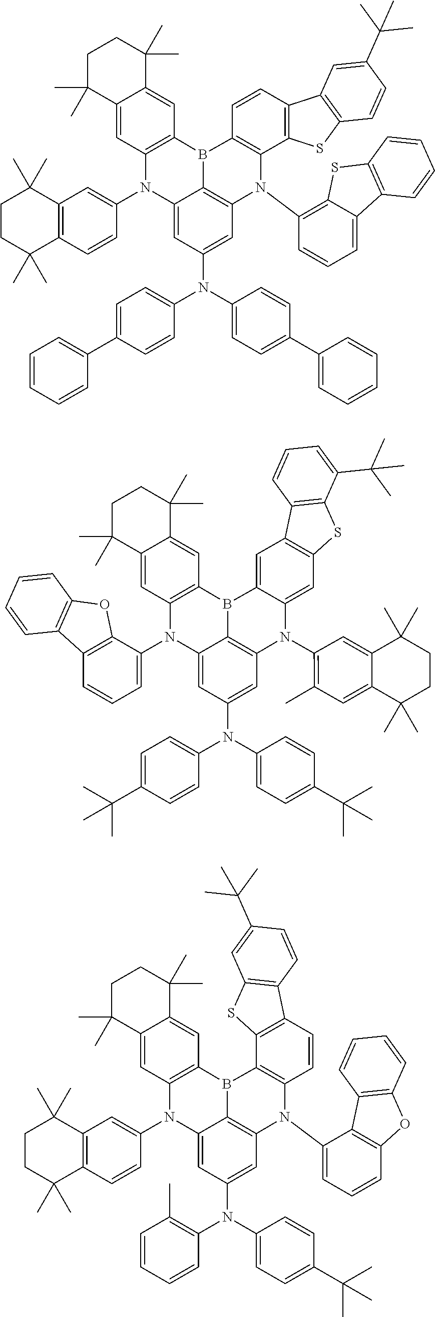 [SMILES: CC(C)(C)c1ccc2sc3c4c(ccc3c2c1)B1c2cc3c(cc2N(c2ccc5c(c2)C(C)(C)CCC5(C)C)c2cc(N(c5ccc(-c6ccccc6)cc5)c5ccc(-c6ccccc6)cc5)cc(c21)N4c1cccc2c1sc1ccccc12)C(C)(C)CCC3(C)C ; Cc1cc2c(cc1N1c3cc4sc5c(C(C)(C)C)cccc5c4cc3B3c4cc5c(cc4N(c4cccc6c4oc4ccccc46)c4cc(N(c6ccc(C(C)(C)C)cc6)c6ccc(C(C)(C)C)cc6)cc1c43)C(C)(C)CCC5(C)C)C(C)(C)CCC2(C)C ; Cc1ccccc1N(c1ccc(C(C)(C)C)cc1)c1cc2c3c(c1)N(c1cccc4oc5ccccc5c14)c1ccc4c(sc5cc(C(C)(C)C)ccc54)c1B3c1cc3c(cc1N2c1ccc2c(c1)C(C)(C)CCC2(C)C)C(C)(C)CCC3(C)C]

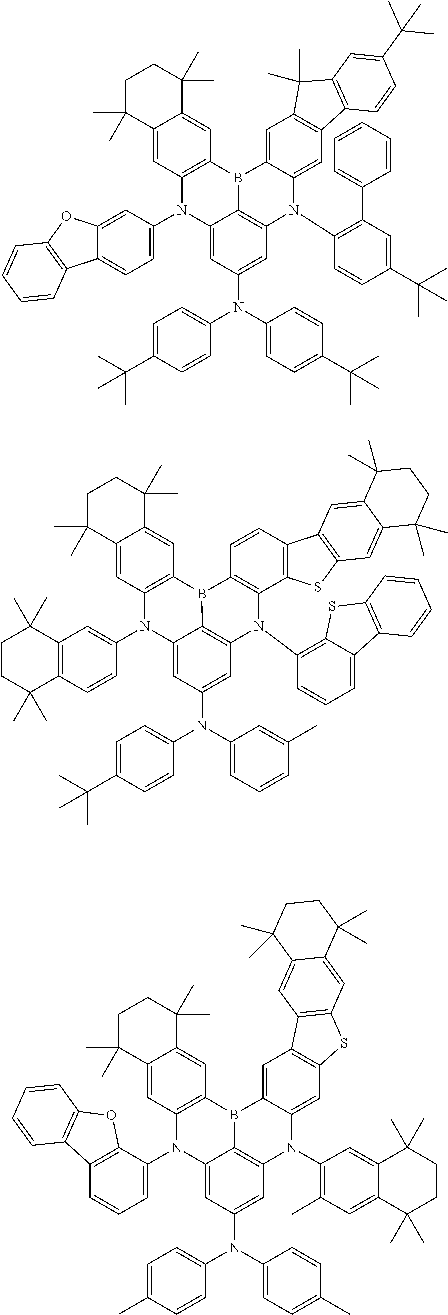

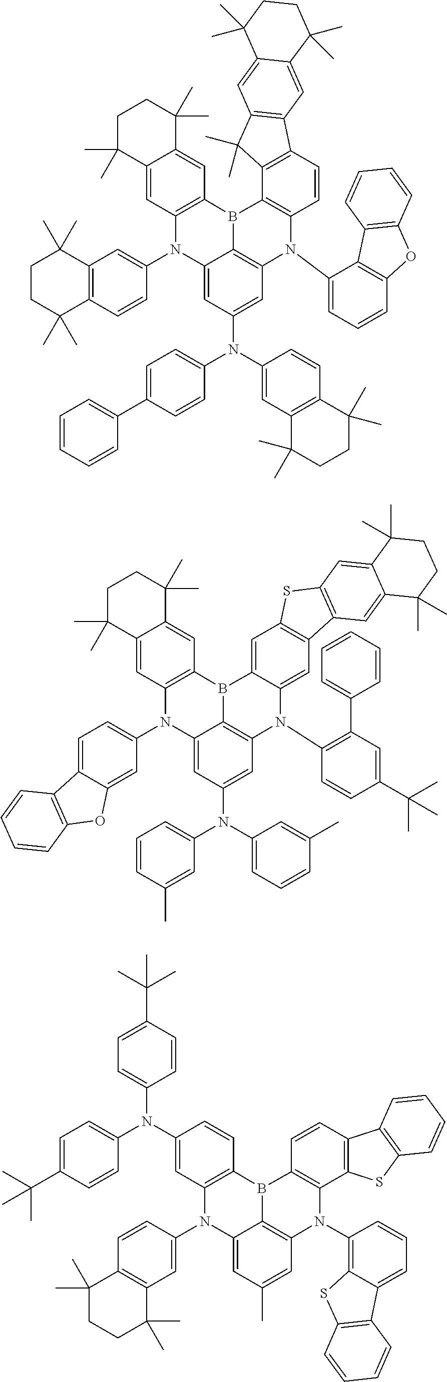

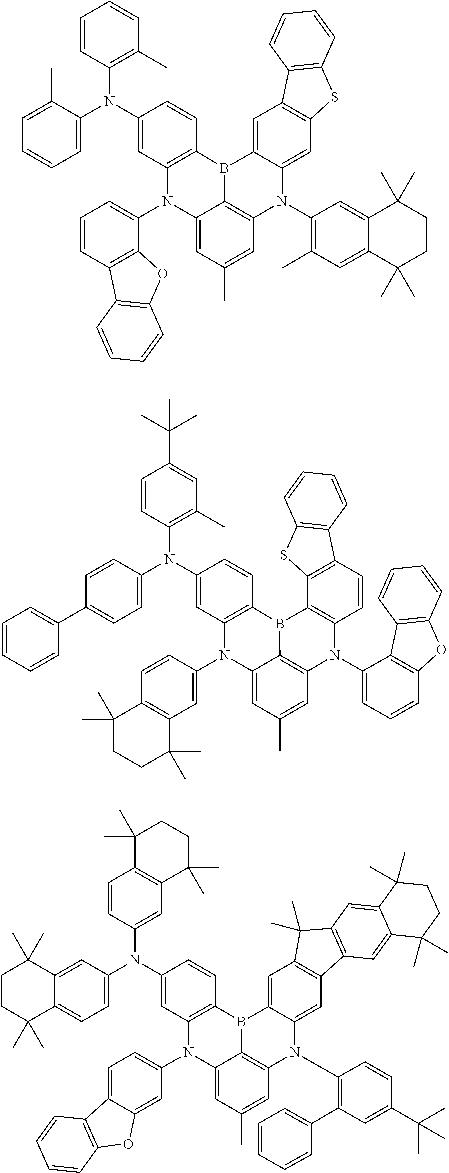 [SMILES: Cc1cc2c3c(c1)N(c1cccc4c1oc1ccccc14)c1cc(N(c4ccccc4C)c4ccccc4C)ccc1B3c1cc3c(cc1N2c1cc2c(cc1C)C(C)(C)CCC2(C)C)sc1ccccc13 ; Cc1cc2c3c(c1)N(c1cccc4oc5ccccc5c14)c1ccc4c(sc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)C(C)(C)c1cc2c(cc1-4)C(C)(C)CCC2(C)C]

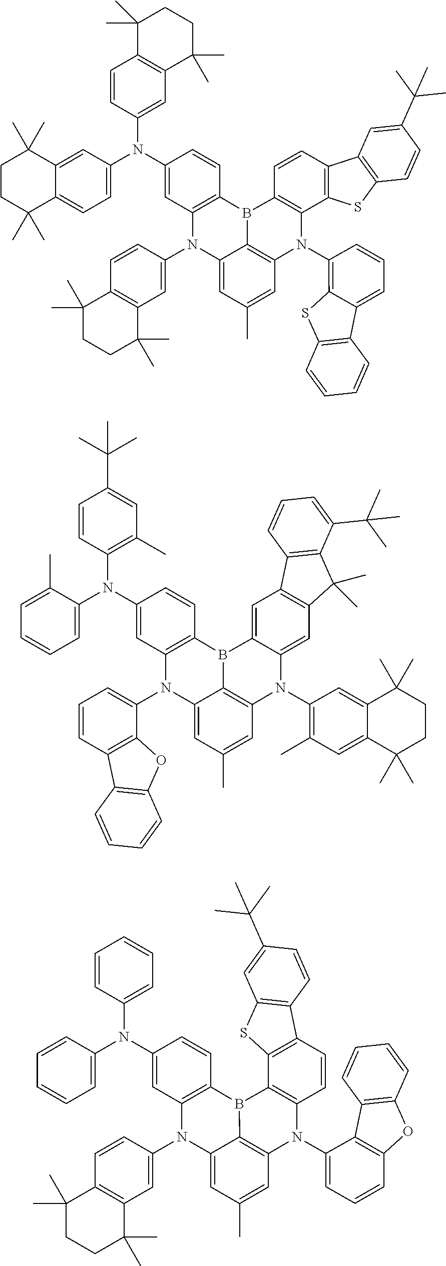

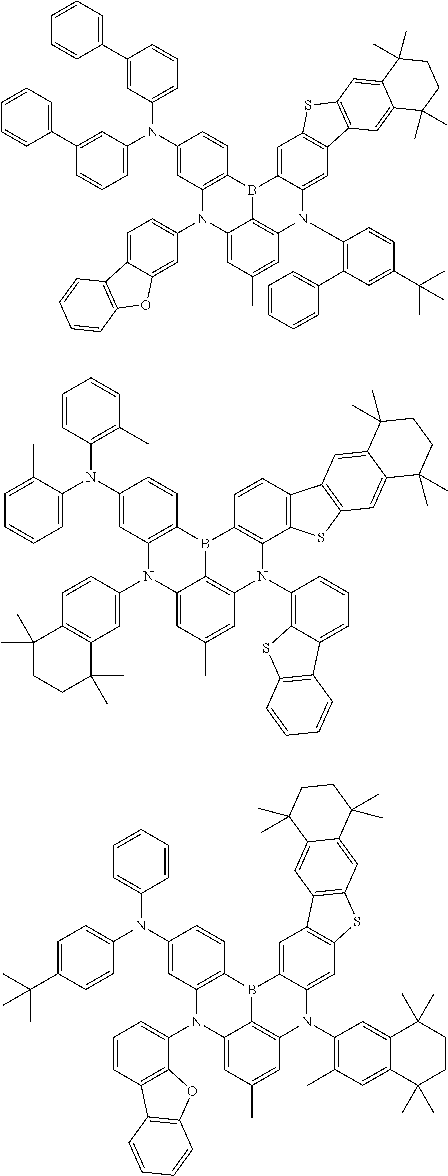

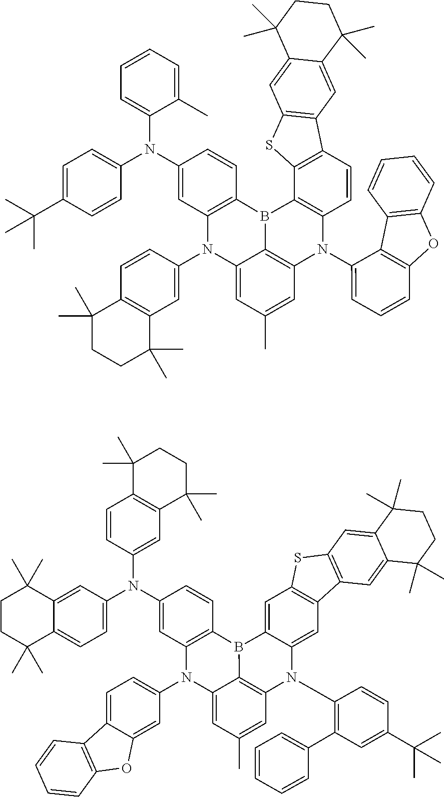 [SMILES: Cc1cc2c3c(c1)N(c1cccc4oc5ccccc5c14)c1ccc4c(sc5cc6c(cc54)C(C)(C)CCC6(C)C)c1B3c1ccc(N(c3ccc(C(C)(C)C)cc3)c3ccccc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)sc1cc2c(cc14)C(C)(C)CCC2(C)C]

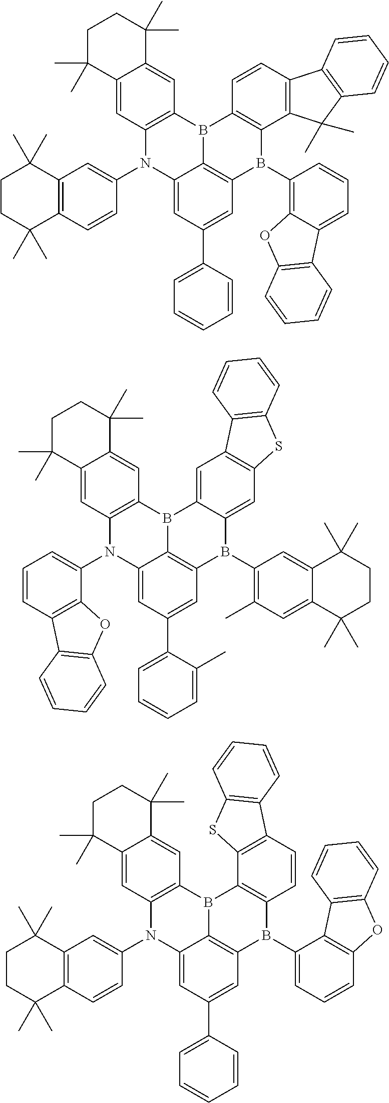

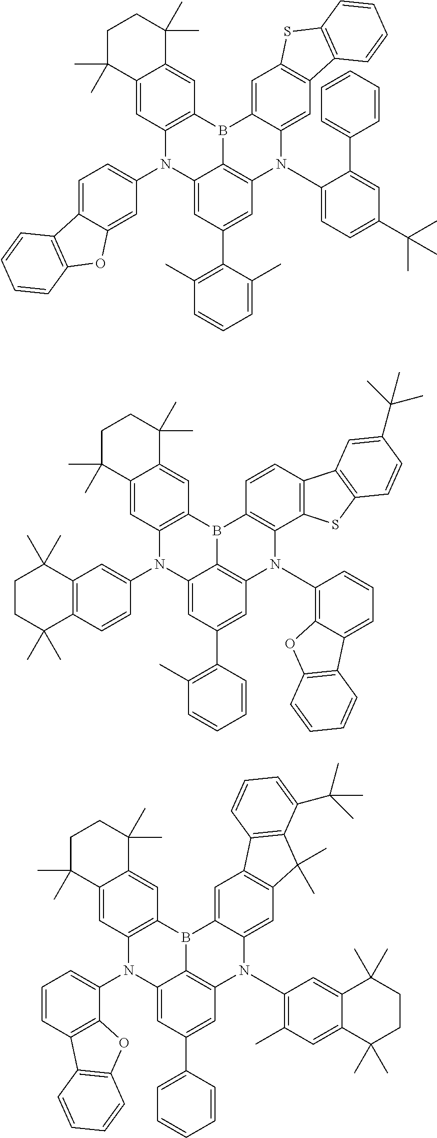

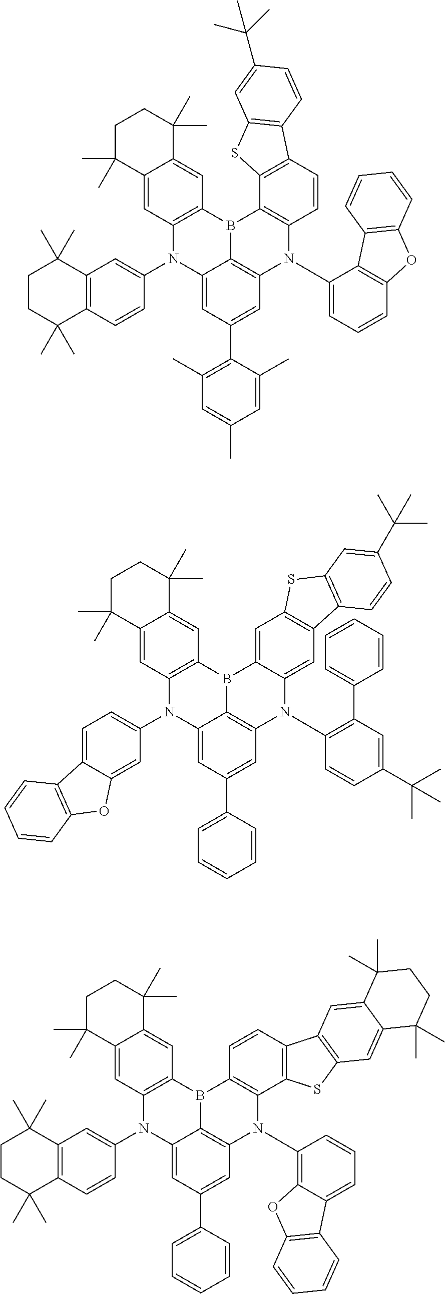 [SMILES: Cc1cc(C)c(-c2cc3c4c(c2)N(c2cccc5oc6ccccc6c25)c2ccc5c(sc6cc(C(C)(C)C)ccc65)c2B4c2cc4c(cc2N3c2ccc3c(c2)C(C)(C)CCC3(C)C)C(C)(C)CCC4(C)C)c(C)c1 ; CC(C)(C)c1ccc(N2c3cc4c(cc3B3c5cc6c(cc5N(c5ccc7c(c5)oc5ccccc57)c5cc(-c7ccccc7)cc2c53)C(C)(C)CCC6(C)C)sc2cc(C(C)(C)C)ccc24)c(-c2ccccc2)c1 ; CC1(C)CCC(C)(C)c2cc(N3c4cc5c(cc4B4c6ccc7c(sc8cc9c(cc87)C(C)(C)CCC9(C)C)c6N(c6cccc7c6oc6ccccc67)c6cc(-c7ccccc7)cc3c64)C(C)(C)CCC5(C)C)ccc21]

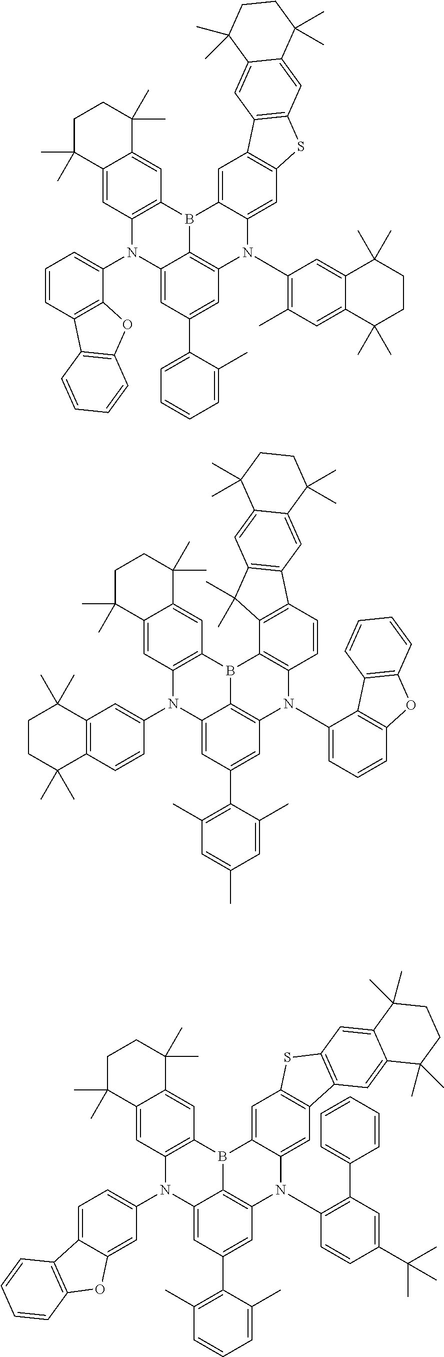 [SMILES: Cc1ccccc1-c1cc2c3c(c1)N(c1cccc4c1oc1ccccc14)c1cc4c(cc1B3c1cc3c(cc1N2c1cc2c(cc1C)C(C)(C)CCC2(C)C)sc1cc2c(cc13)C(C)(C)CCC2(C)C)C(C)(C)CCC4(C)C ; Cc1cc(C)c(-c2cc3c4c(c2)N(c2cccc5oc6ccccc6c25)c2ccc5c(c2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)sc1cc2c(cc14)C(C)(C)CCC2(C)C]

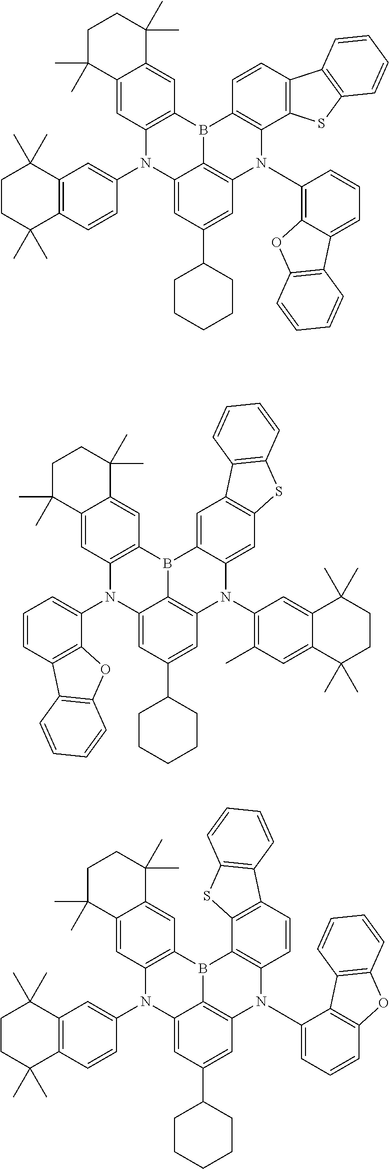 [SMILES: CC1(C)CCC(C)(C)c2cc(N3c4cc5c(cc4B4c6ccc7c(sc8ccccc87)c6N(c6cccc7c6oc6ccccc67)c6cc(C7CCCCC7)cc3c64)C(C)(C)CCC5(C)C)ccc21 ; Cc1cc2c(cc1N1c3cc4sc5ccccc5c4cc3B3c4cc5c(cc4N(c4cccc6c4oc4ccccc46)c4cc(C6CCCCC6)cc1c43)C(C)(C)CCC5(C)C)C(C)(C)CCC2(C)C ; CC1(C)CCC(C)(C)c2cc(N3c4cc5c(cc4B4c6c3cc(C3CCCCC3)cc6N(c3cccc6oc7ccccc7c36)c3ccc6c(sc7ccccc76)c34)C(C)(C)CCC5(C)C)ccc21]

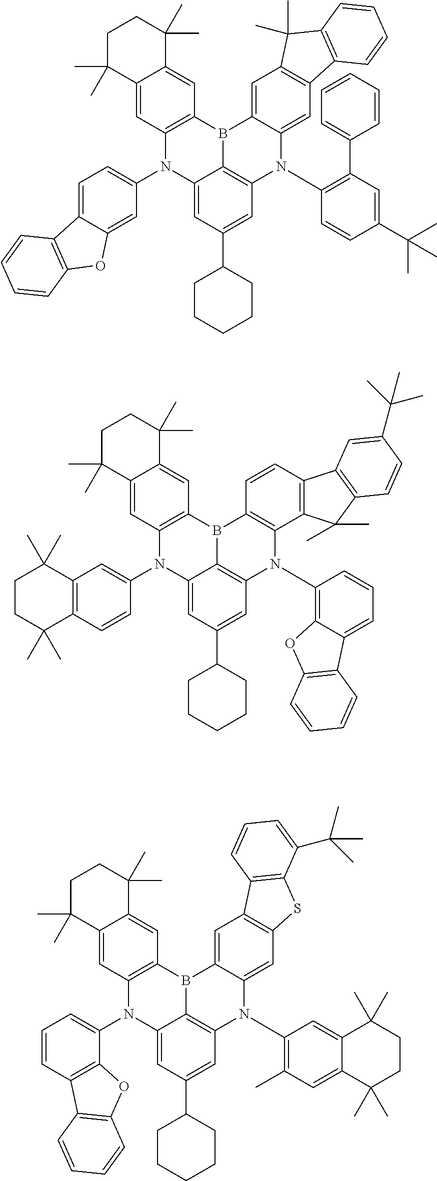

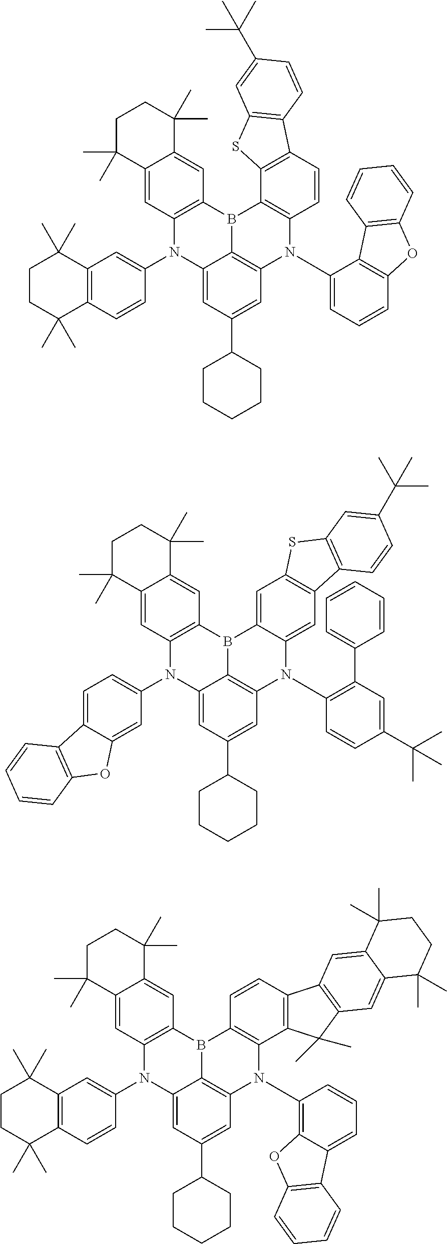 [SMILES: CC(C)(C)c1ccc2c(c1)sc1c3c(ccc12)N(c1cccc2oc4ccccc4c12)c1cc(C2CCCCC2)cc2c1B3c1cc3c(cc1N2c1ccc2c(c1)C(C)(C)CCC2(C)C)C(C)(C)CCC3(C)C ; CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)sc2cc(C(C)(C)C)ccc24)c(-c2ccccc2)c1 ; CC1(C)CCC(C)(C)c2cc(N3c4cc5c(cc4B4c6ccc7c(c6N(c6cccc8c6oc6ccccc68)c6cc(C8CCCCC8)cc3c64)C(C)(C)c3cc4c(cc3-7)C(C)(C)CCC4(C)C)C(C)(C)CCC5(C)C)ccc21]

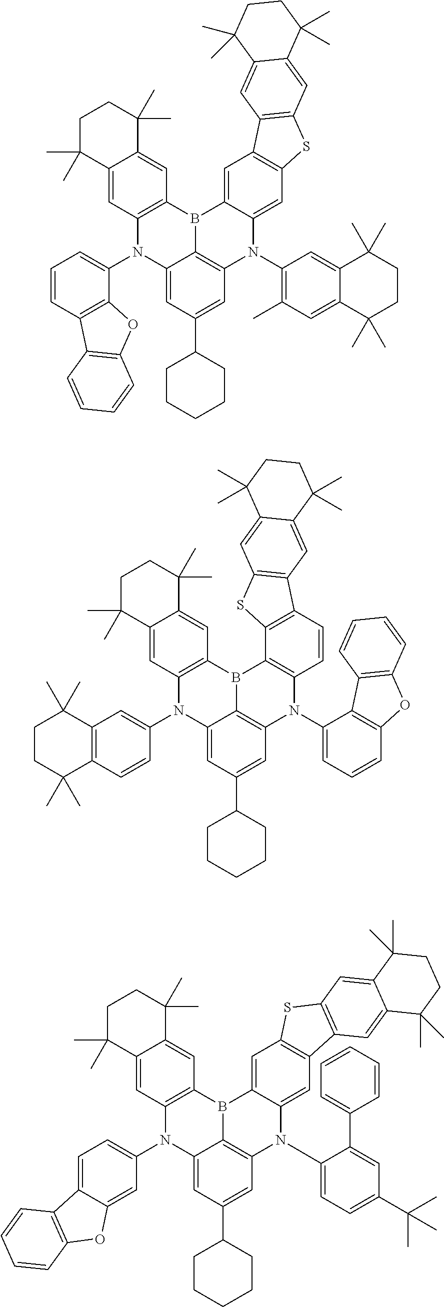 [SMILES: Cc1cc2c(cc1N1c3cc4sc5cc6c(cc5c4cc3B3c4cc5c(cc4N(c4cccc7c4oc4ccccc47)c4cc(C7CCCCC7)cc1c43)C(C)(C)CCC5(C)C)C(C)(C)CCC6(C)C)C(C)(C)CCC2(C)C ; CC1(C)CCC(C)(C)c2cc(N3c4cc5c(cc4B4c6c3cc(C3CCCCC3)cc6N(c3cccc6oc7ccccc7c36)c3ccc6c(sc7cc8c(cc76)C(C)(C)CCC8(C)C)c34)C(C)(C)CCC5(C)C)ccc21 ; CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)sc2cc3c(cc24)C(C)(C)CCC3(C)C)c(-c2ccccc2)c1]

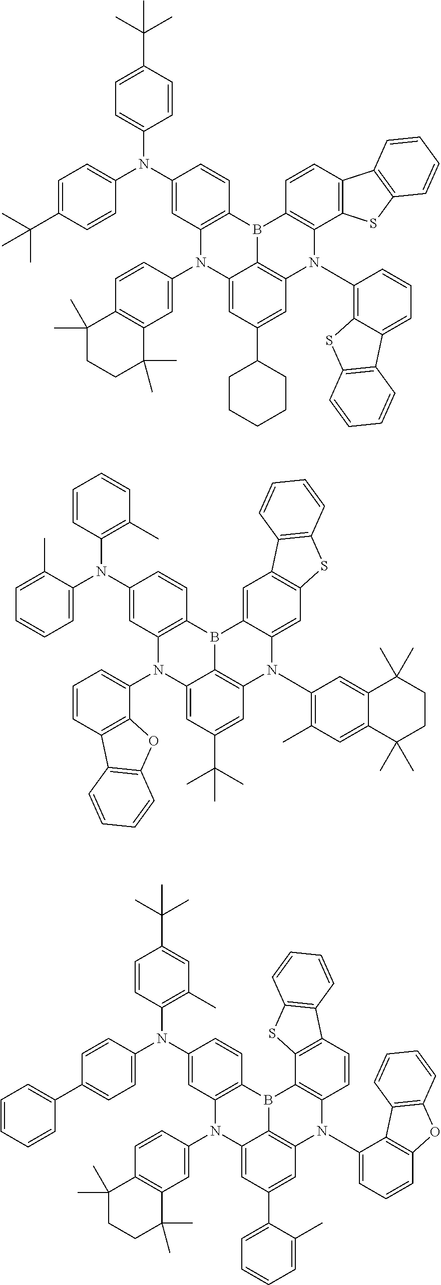 [SMILES: CC(C)(C)c1ccc(N(c2ccc(C(C)(C)C)cc2)c2ccc3c(c2)N(c2ccc4c(c2)C(C)(C)CCC4(C)C)c2cc(C4CCCCC4)cc4c2B3c2ccc3c(sc5ccccc53)c2N4c2cccc3c2sc2ccccc23)cc1 ; Cc1ccccc1N(c1ccc2c(c1)N(c1cccc3c1oc1ccccc13)c1cc(C(C)(C)C)cc3c1B2c1cc2c(cc1N3c1cc3c(cc1C)C(C)(C)CCC3(C)C)sc1ccccc12)c1ccccc1C ; Cc1ccccc1-c1cc2c3c(c1)N(c1cccc4oc5ccccc5c14)c1ccc4c(sc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C]

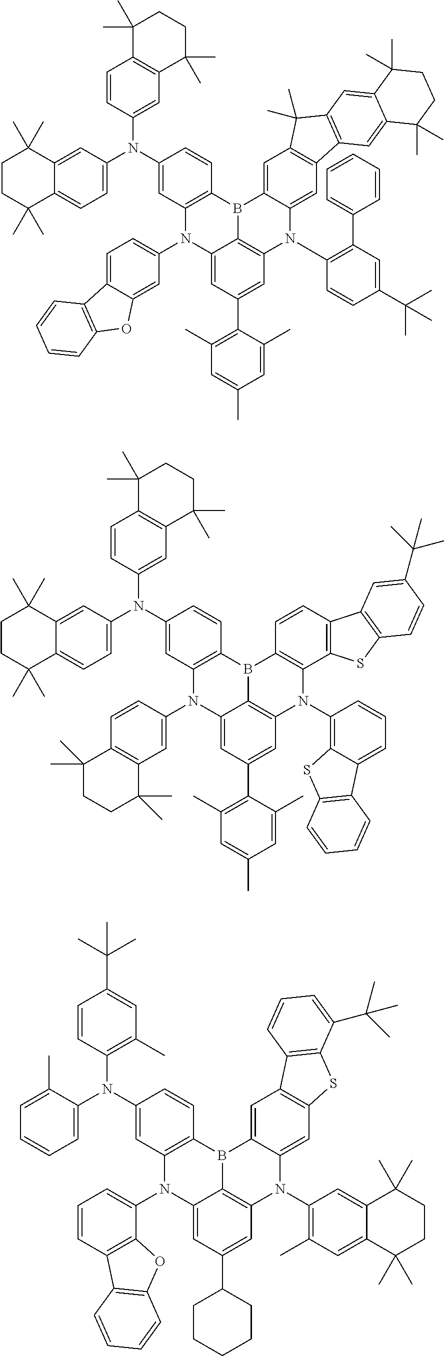

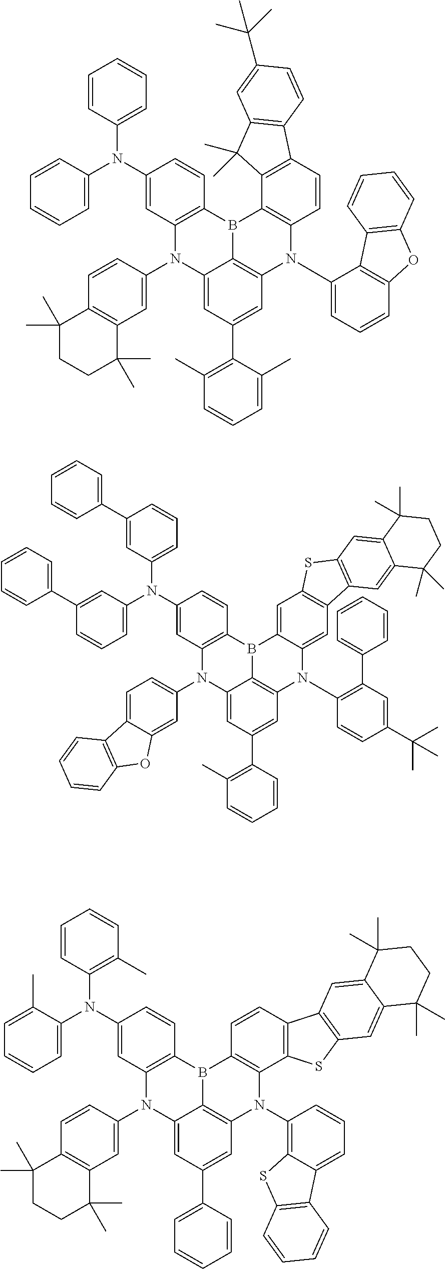

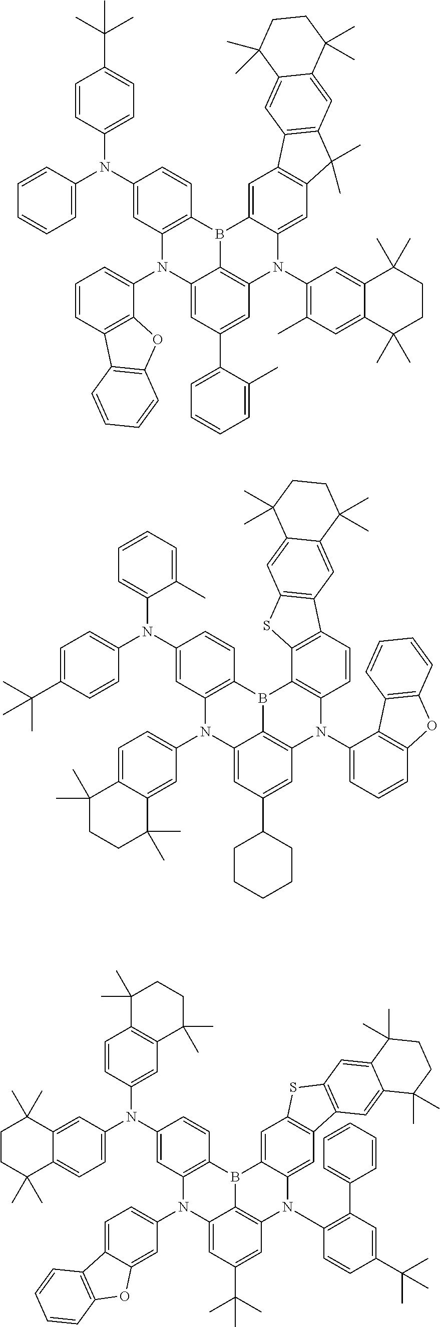 [SMILES: Cc1ccccc1-c1cc2c3c(c1)N(c1cccc4c1oc1ccccc14)c1cc(N(c4ccccc4)c4ccc(C(C)(C)C)cc4)ccc1B3c1cc3c(cc1N2c1cc2c(cc1C)C(C)(C)CCC2(C)C)C(C)(C)c1cc2c(cc1-3)C(C)(C)CCC2(C)C ; Cc1ccccc1N(c1ccc(C(C)(C)C)cc1)c1ccc2c(c1)N(c1ccc3c(c1)C(C)(C)CCC3(C)C)c1cc(C3CCCCC3)cc3c1B2c1c(ccc2c1sc1cc4c(cc12)C(C)(C)CCC4(C)C)N3c1cccc2oc3ccccc3c12 ; CC(C)(C)c1ccc(N2c3cc4c(cc3B3c5ccc(N(c6ccc7c(c6)C(C)(C)CCC7(C)C)c6ccc7c(c6)C(C)(C)CCC7(C)C)cc5N(c5ccc6c(c5)oc5ccccc56)c5cc(C(C)(C)C)cc2c53)sc2cc3c(cc24)C(C)(C)CCC3(C)C)c(-c2ccccc2)c1]

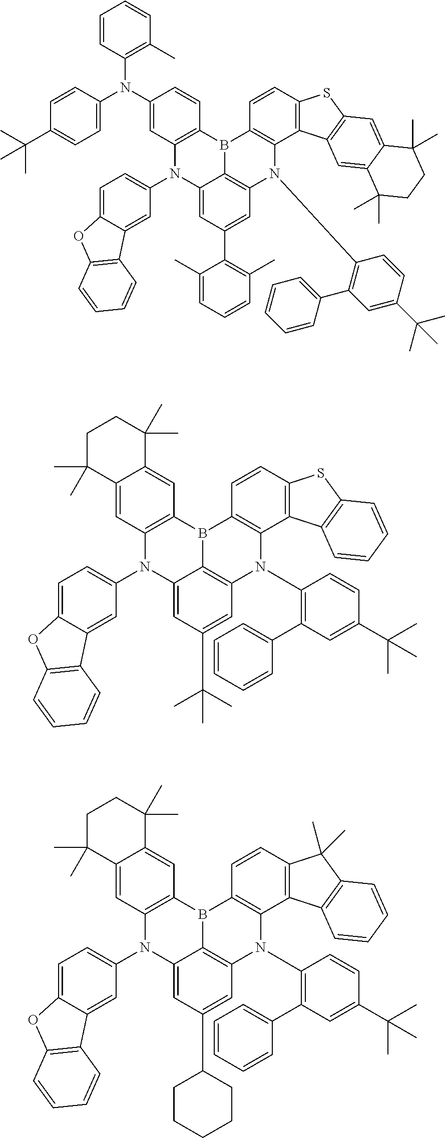 [SMILES: Cc1ccccc1N(c1ccc(C(C)(C)C)cc1)c1ccc2c(c1)N(c1ccc3oc4ccccc4c3c1)c1cc(-c3c(C)cccc3C)cc3c1B2c1ccc2sc4cc5c(cc4c2c1N3c1ccc(C(C)(C)C)cc1-c1ccccc1)C(C)(C)CCC5(C)C ; CC(C)(C)c1ccc(N2c3cc(C(C)(C)C)cc4c3B(c3cc5c(cc3N4c3ccc4oc6ccccc6c4c3)C(C)(C)CCC5(C)C)c3ccc4sc5ccccc5c4c32)c(-c2ccccc2)c1 ; CC(C)(C)c1ccc(N2c3cc(C4CCCCC4)cc4c3B(c3cc5c(cc3N4c3ccc4oc6ccccc6c4c3)C(C)(C)CCC5(C)C)c3ccc4c(c32)-c2ccccc2C4(C)C)c(-c2ccccc2)c1]

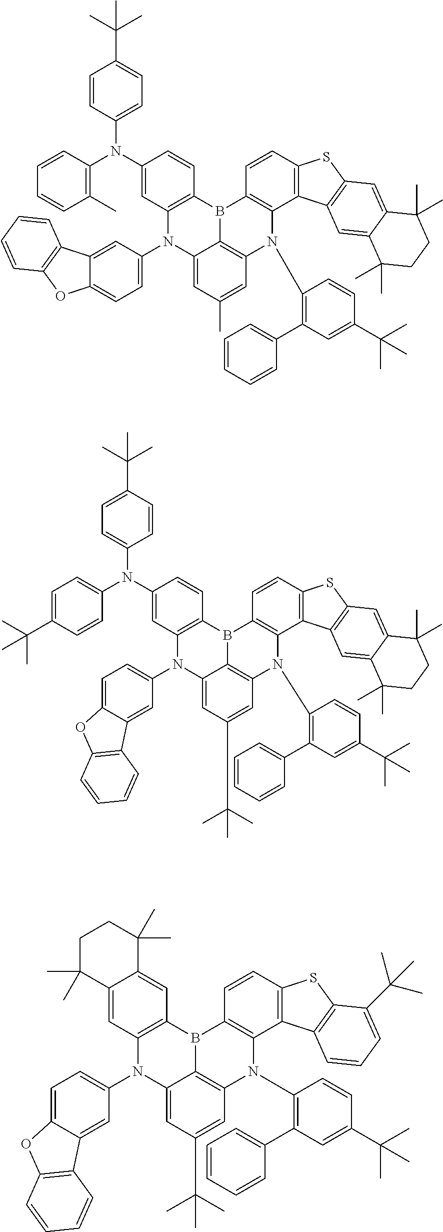

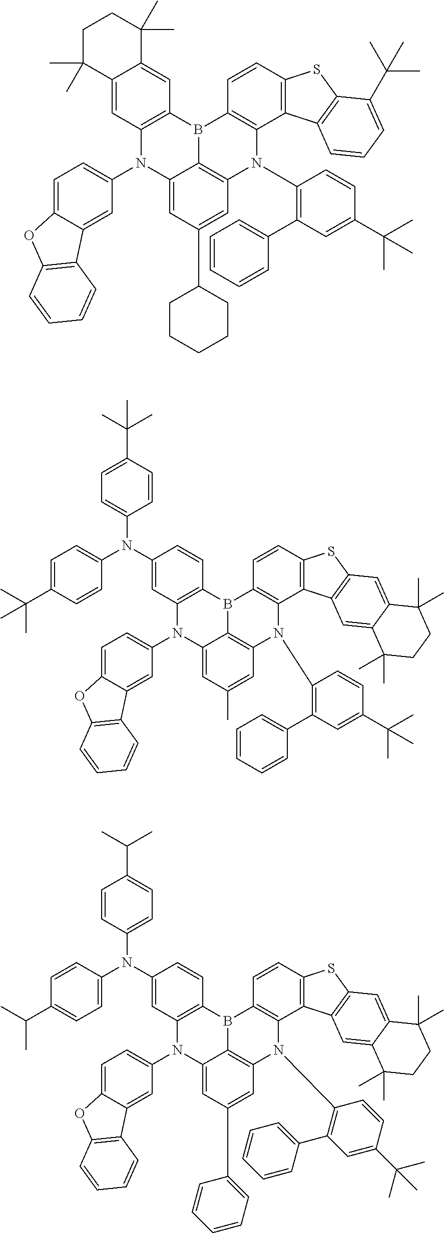

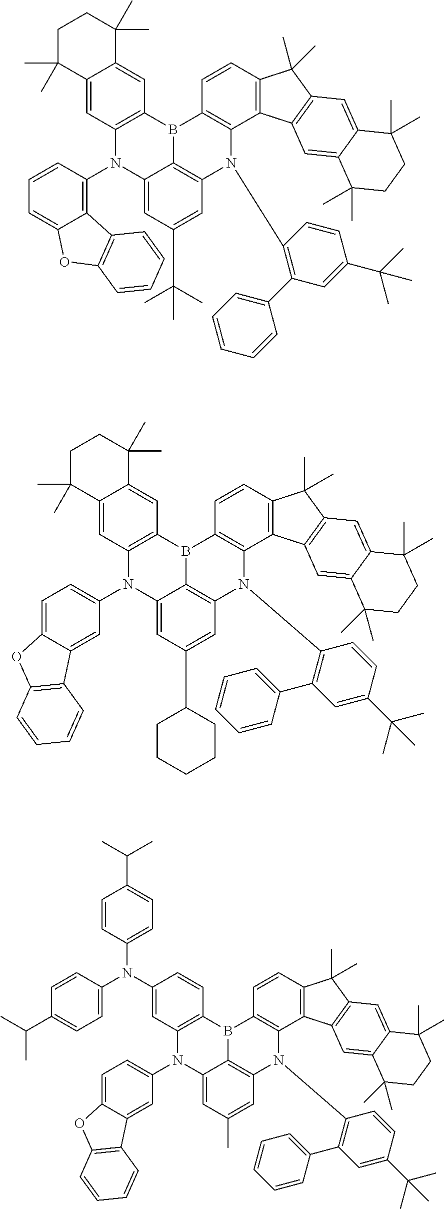

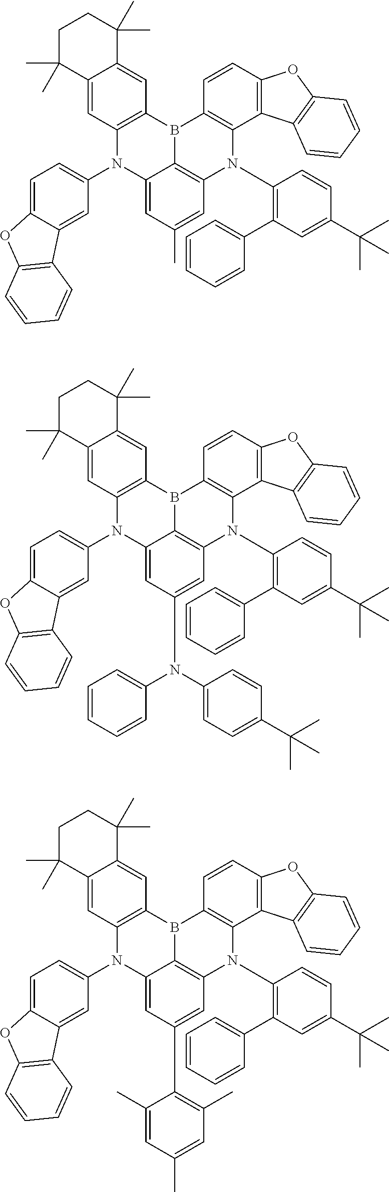 [SMILES: Cc1cc2c3c(c1)N(c1ccc(C(C)(C)C)cc1-c1ccccc1)c1c(ccc4oc5ccccc5c14)B3c1cc3c(cc1N2c1ccc2oc4ccccc4c2c1)C(C)(C)CCC3(C)C ; CC(C)(C)c1ccc(N(c2ccccc2)c2cc3c4c(c2)N(c2ccc(C(C)(C)C)cc2-c2ccccc2)c2c(ccc5oc6ccccc6c25)B4c2cc4c(cc2N3c2ccc3oc5ccccc5c3c2)C(C)(C)CCC4(C)C)cc1 ; Cc1cc(C)c(-c2cc3c4c(c2)N(c2ccc(C(C)(C)C)cc2-c2ccccc2)c2c(ccc5oc6ccccc6c25)B4c2cc4c(cc2N3c2ccc3oc5ccccc5c3c2)C(C)(C)CCC4(C)C)c(C)c1]

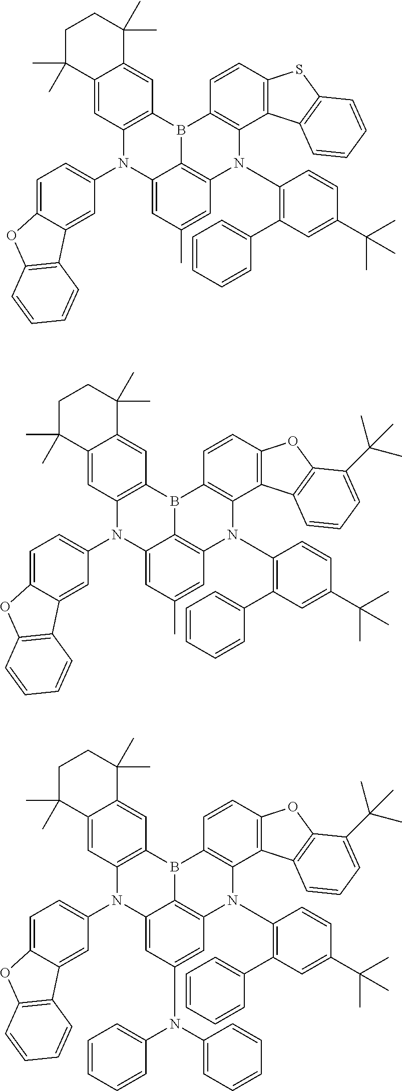 [SMILES: Cc1cc2c3c(c1)N(c1ccc(C(C)(C)C)cc1-c1ccccc1)c1c(ccc4sc5ccccc5c14)B3c1cc3c(cc1N2c1ccc2oc4ccccc4c2c1)C(C)(C)CCC3(C)C ; Cc1cc2c3c(c1)N(c1ccc(C(C)(C)C)cc1-c1ccccc1)c1c(ccc4oc5c(C(C)(C)C)cccc5c14)B3c1cc3c(cc1N2c1ccc2oc4ccccc4c2c1)C(C)(C)CCC3(C)C ; CC(C)(C)c1ccc(N2c3cc(N(c4ccccc4)c4ccccc4)cc4c3B(c3cc5c(cc3N4c3ccc4oc6ccccc6c4c3)C(C)(C)CCC5(C)C)c3ccc4oc5c(C(C)(C)C)cccc5c4c32)c(-c2ccccc2)c1]

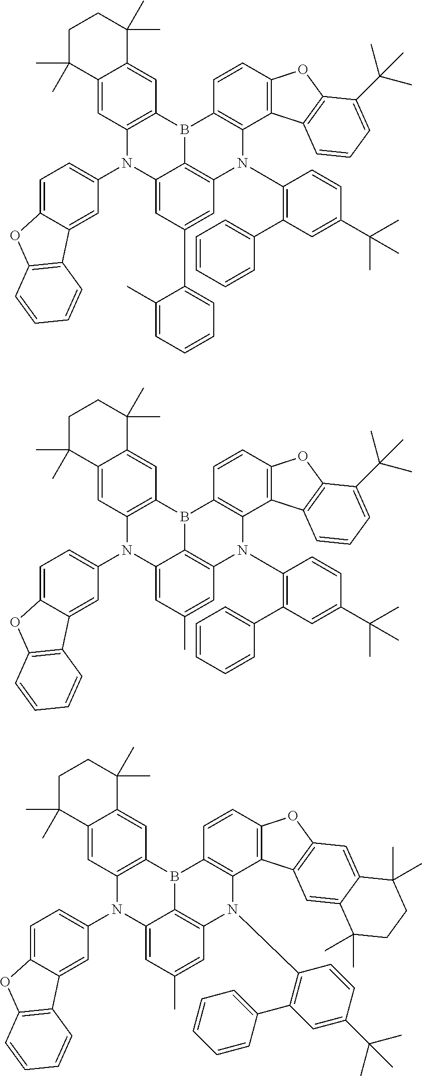 [SMILES: Cc1ccccc1-c1cc2c3c(c1)N(c1ccc(C(C)(C)C)cc1-c1ccccc1)c1c(ccc4oc5c(C(C)(C)C)cccc5c14)B3c1cc3c(cc1N2c1ccc2oc4ccccc4c2c1)C(C)(C)CCC3(C)C ; Cc1cc2c3c(c1)N(c1ccc(C(C)(C)C)cc1-c1ccccc1)c1c(ccc4oc5c(C(C)(C)C)cccc5c14)B3c1cc3c(cc1N2c1ccc2oc4ccccc4c2c1)C(C)(C)CCC3(C)C ; Cc1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc2oc4ccccc4c2c1)C(C)(C)CCC3(C)C]

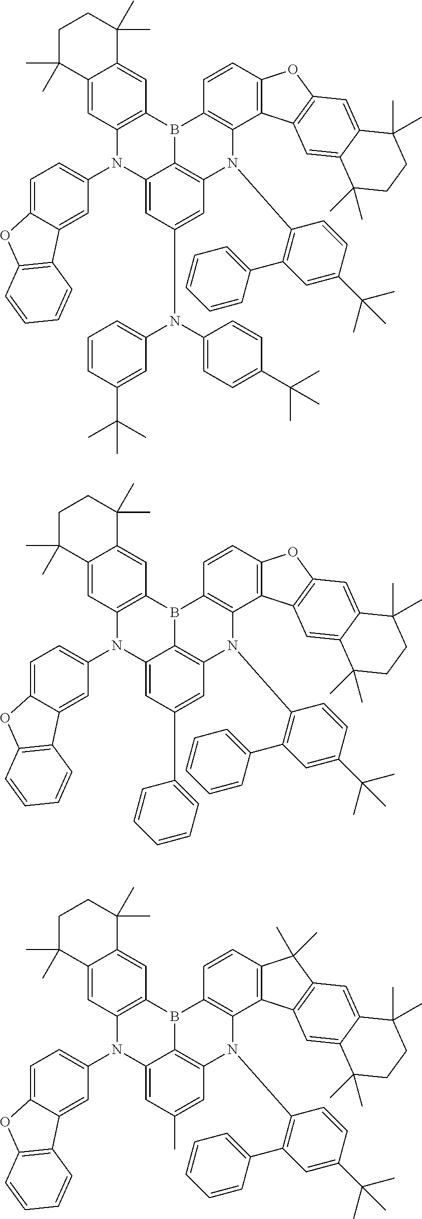

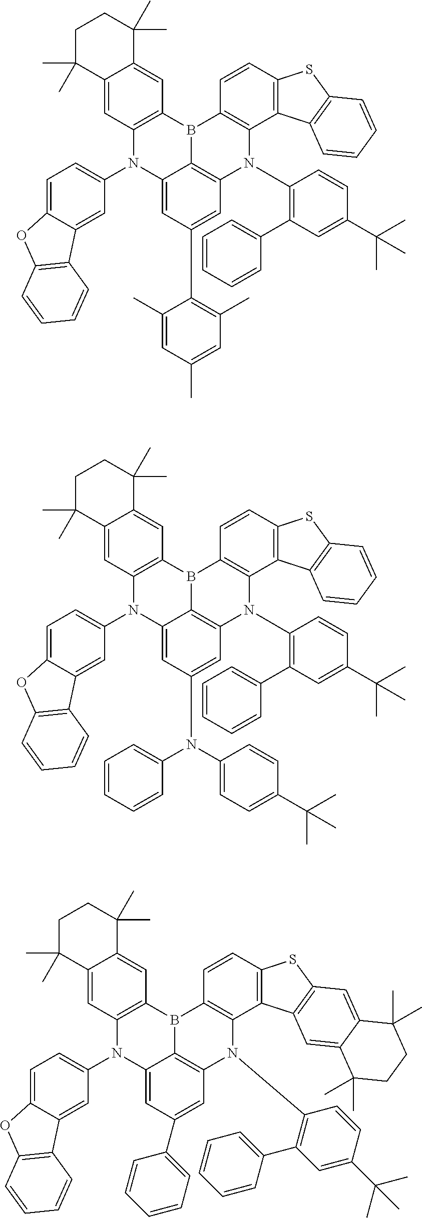 [SMILES: Cc1cc(C)c(-c2cc3c4c(c2)N(c2ccc(C(C)(C)C)cc2-c2ccccc2)c2c(ccc5sc6ccccc6c25)B4c2cc4c(cc2N3c2ccc3oc5ccccc5c3c2)C(C)(C)CCC4(C)C)c(C)c1 ; CC(C)(C)c1ccc(N(c2ccccc2)c2cc3c4c(c2)N(c2ccc(C(C)(C)C)cc2-c2ccccc2)c2c(ccc5sc6ccccc6c25)B4c2cc4c(cc2N3c2ccc3oc5ccccc5c3c2)C(C)(C)CCC4(C)C)cc1 ; CC(C)(C)c1ccc(N2c3cc(-c4ccccc4)cc4c3B(c3cc5c(cc3N4c3ccc4oc6ccccc6c4c3)C(C)(C)CCC5(C)C)c3ccc4sc5cc6c(cc5c4c32)C(C)(C)CCC6(C)C)c(-c2ccccc2)c1]

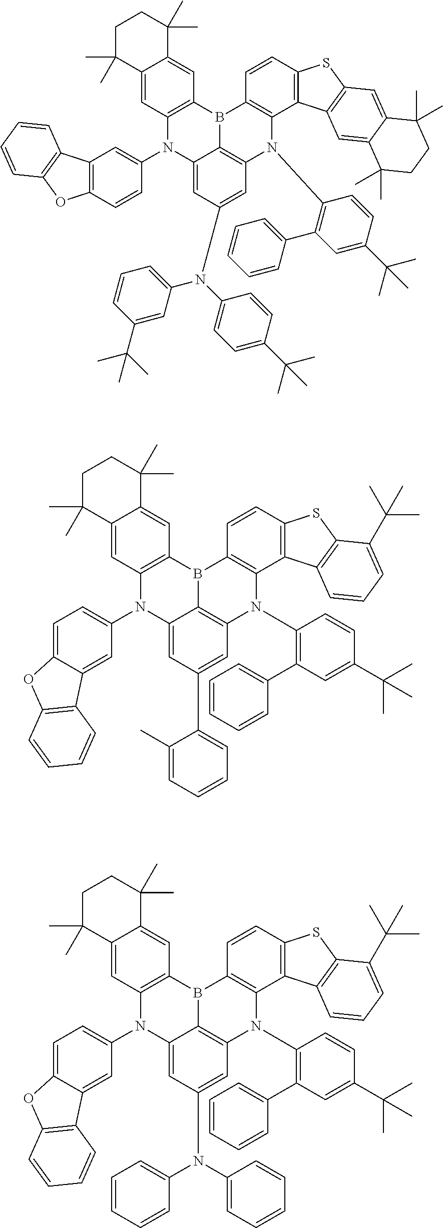 [SMILES: CC(C)(C)c1ccc(N(c2cccc(C(C)(C)C)c2)c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc3oc5ccccc5c3c2)C(C)(C)CCC4(C)C)cc1 ; Cc1ccccc1-c1cc2c3c(c1)N(c1ccc(C(C)(C)C)cc1-c1ccccc1)c1c(ccc4sc5c(C(C)(C)C)cccc5c14)B3c1cc3c(cc1N2c1ccc2oc4ccccc4c2c1)C(C)(C)CCC3(C)C ; CC(C)(C)c1ccc(N2c3cc(N(c4ccccc4)c4ccccc4)cc4c3B(c3cc5c(cc3N4c3ccc4oc6ccccc6c4c3)C(C)(C)CCC5(C)C)c3ccc4sc5c(C(C)(C)C)cccc5c4c32)c(-c2ccccc2)c1]

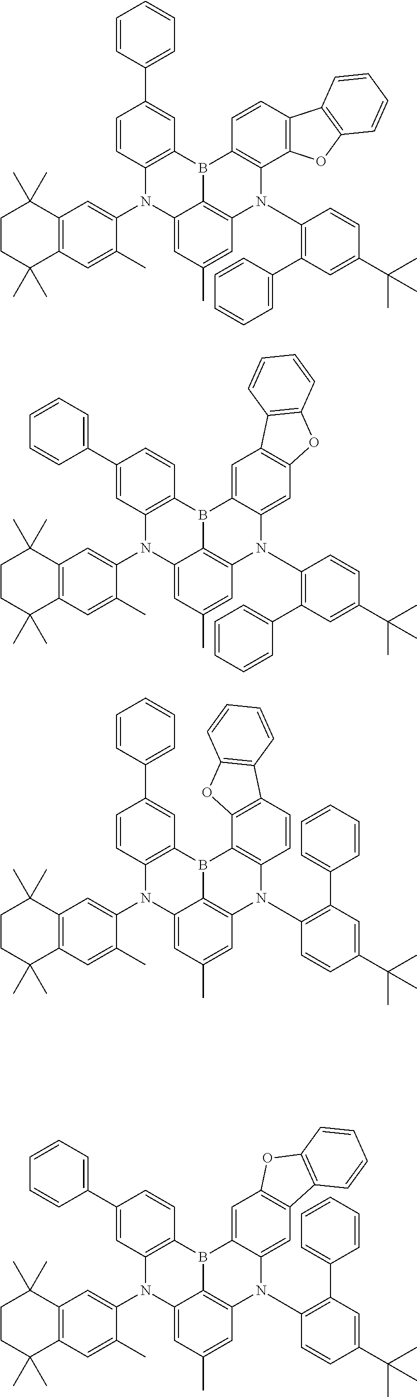

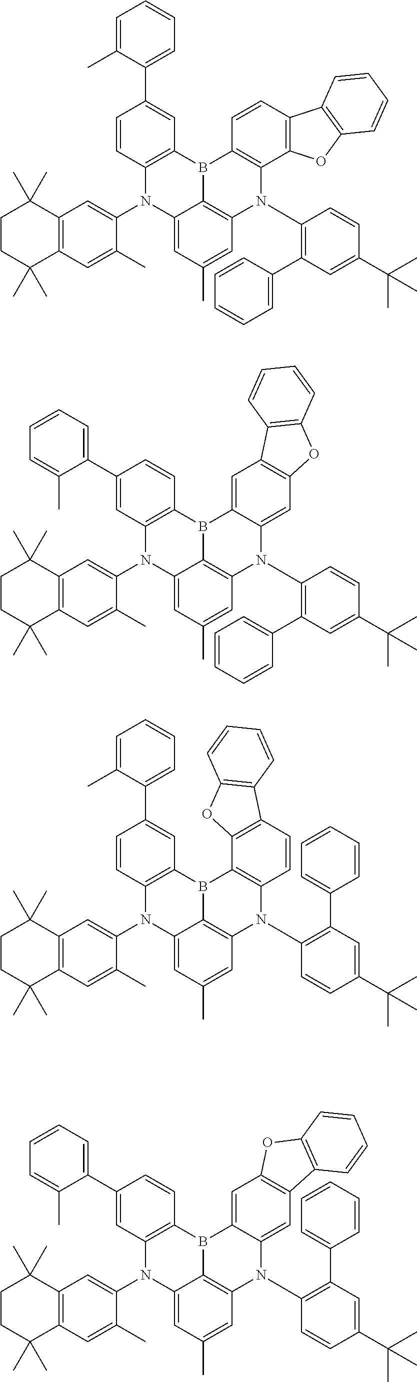

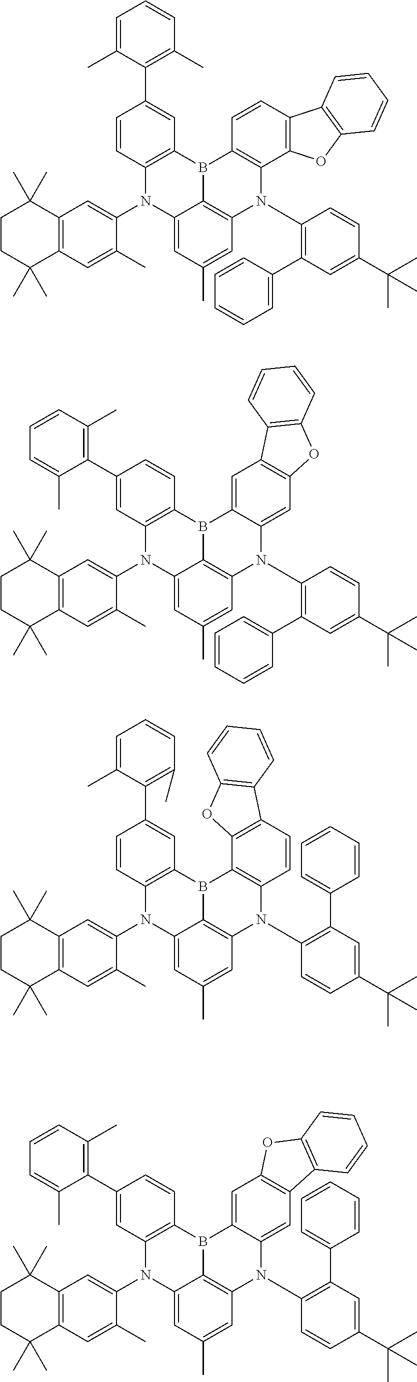

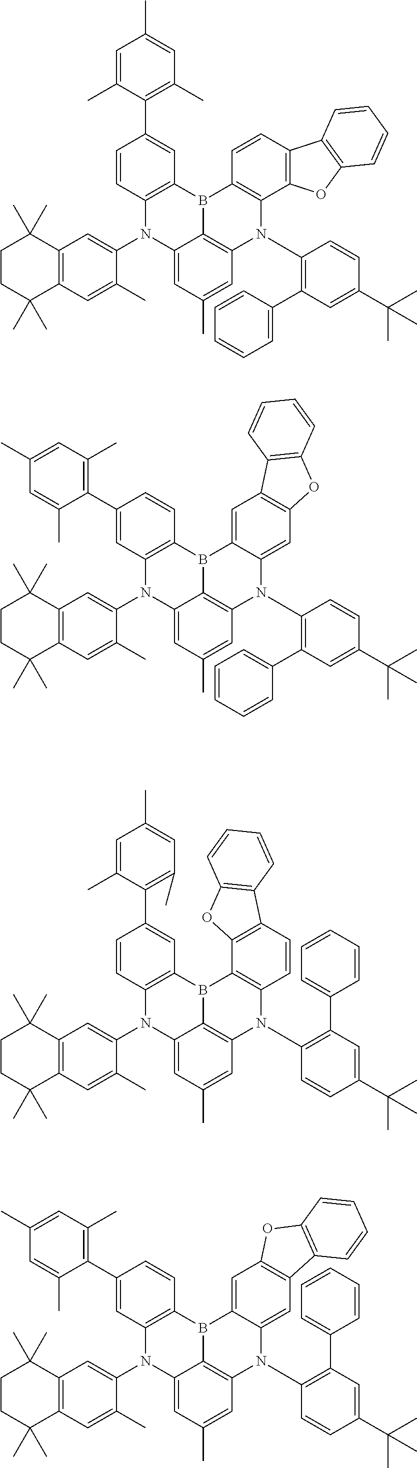

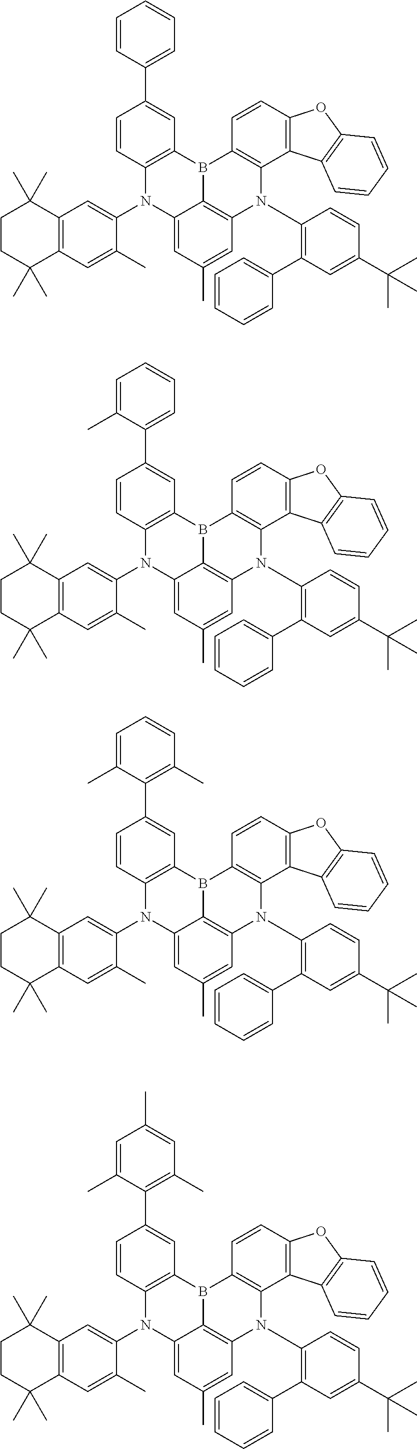 [SMILES: Cc1cc2c3c(c1)N(c1ccc(C(C)(C)C)cc1-c1ccccc1)c1c(ccc4oc5ccccc5c14)B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1c(ccc4oc5ccccc5c14)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1c(ccc4oc5ccccc5c14)B3c1cc(-c3c(C)cccc3C)ccc1N2c1cc2c(cc1C)C(C)(C)CCC2(C)C ; Cc1cc(C)c(-c2ccc3c(c2)B2c4ccc5oc6ccccc6c5c4N(c4ccc(C(C)(C)C)cc4-c4ccccc4)c4cc(C)cc(c42)N3c2cc3c(cc2C)C(C)(C)CCC3(C)C)c(C)c1]

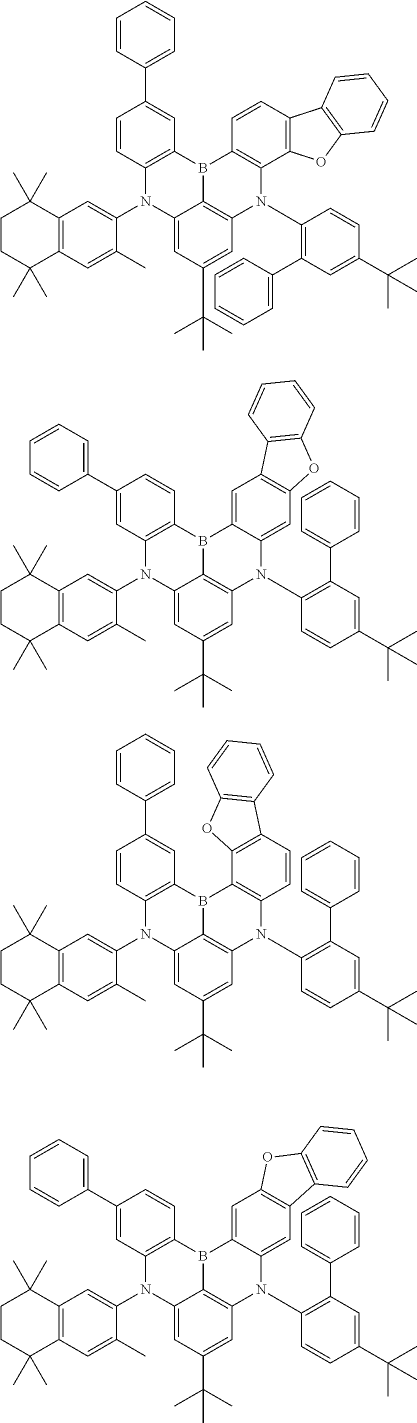

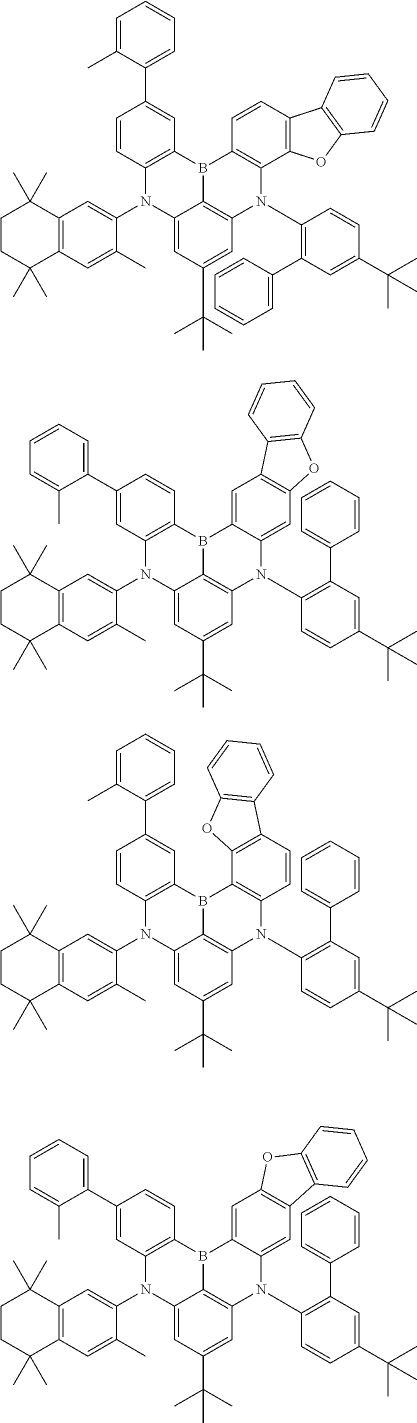

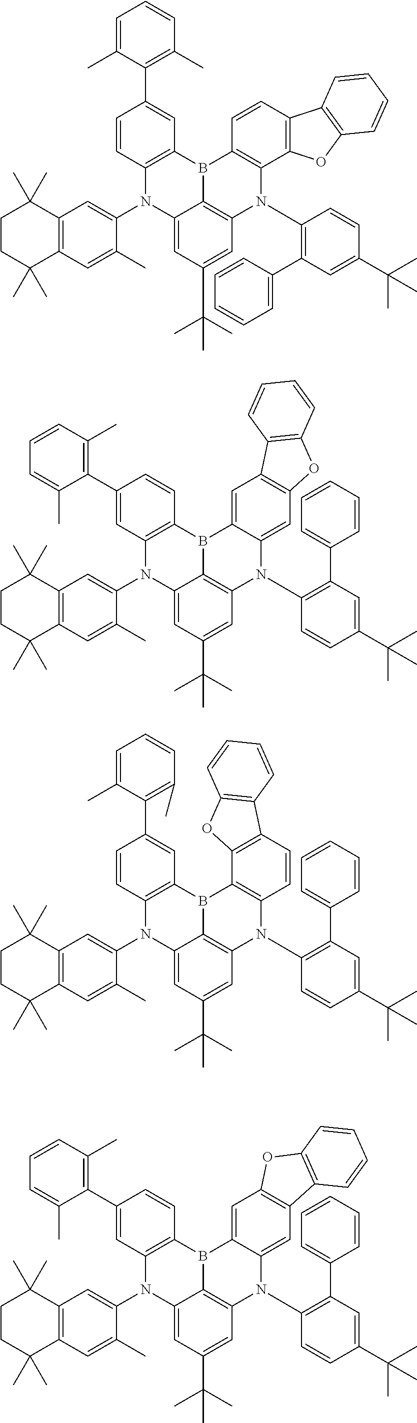

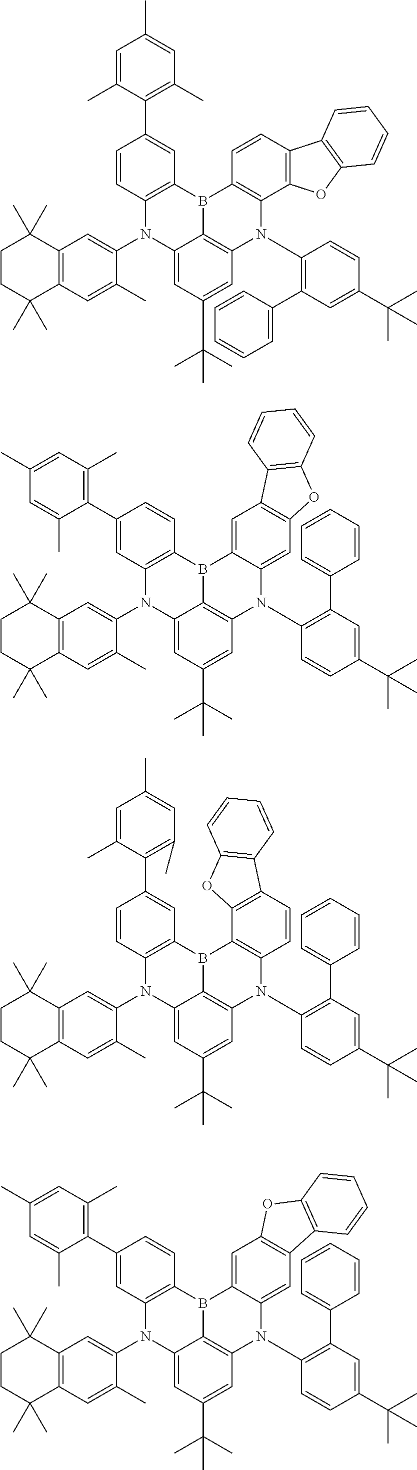

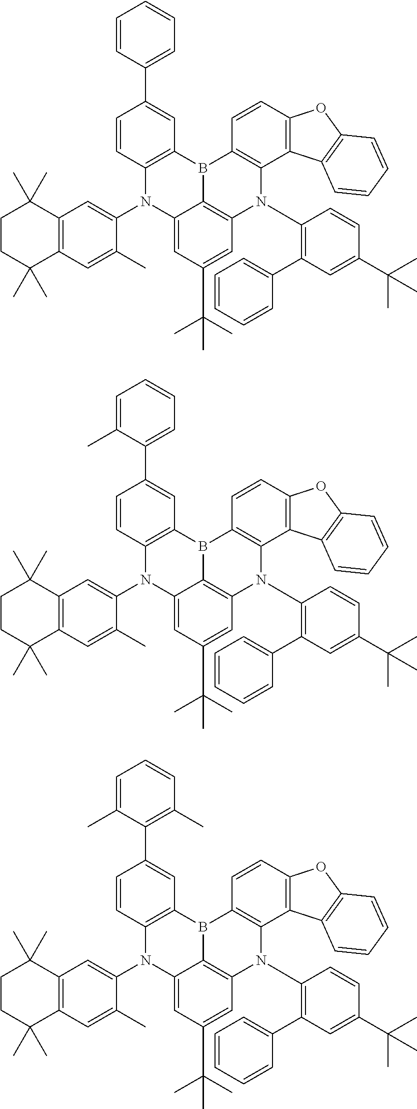 [SMILES: Cc1cc2c(cc1N1c3ccc(-c4ccccc4)cc3B3c4ccc5oc6ccccc6c5c4N(c4ccc(C(C)(C)C)cc4-c4ccccc4)c4cc(C(C)(C)C)cc1c43)C(C)(C)CCC2(C)C ; Cc1ccccc1-c1ccc2c(c1)B1c3ccc4oc5ccccc5c4c3N(c3ccc(C(C)(C)C)cc3-c3ccccc3)c3cc(C(C)(C)C)cc(c31)N2c1cc2c(cc1C)C(C)(C)CCC2(C)C ; Cc1cc2c(cc1N1c3ccc(-c4c(C)cccc4C)cc3B3c4ccc5oc6ccccc6c5c4N(c4ccc(C(C)(C)C)cc4-c4ccccc4)c4cc(C(C)(C)C)cc1c43)C(C)(C)CCC2(C)C]

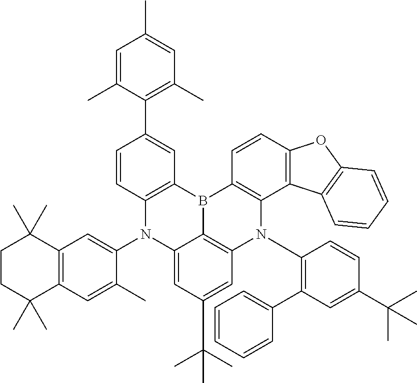 [SMILES: Cc1cc(C)c(-c2ccc3c(c2)B2c4ccc5oc6ccccc6c5c4N(c4ccc(C(C)(C)C)cc4-c4ccccc4)c4cc(C(C)(C)C)cc(c42)N3c2cc3c(cc2C)C(C)(C)CCC3(C)C)c(C)c1]

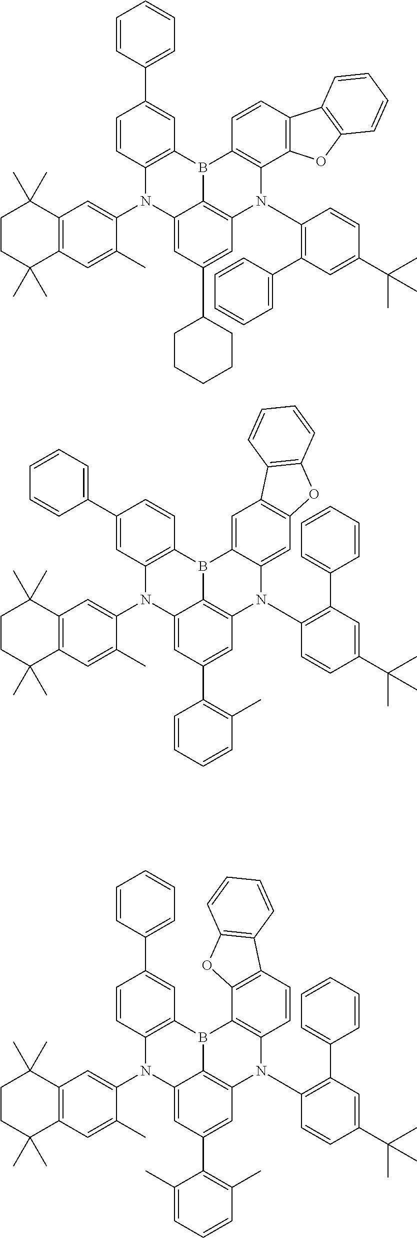 [SMILES: Cc1cc2c(cc1N1c3ccc(-c4ccccc4)cc3B3c4ccc5c(oc6ccccc65)c4N(c4ccc(C(C)(C)C)cc4-c4ccccc4)c4cc(C5CCCCC5)cc1c43)C(C)(C)CCC2(C)C ; Cc1ccccc1-c1cc2c3c(c1)N(c1ccc(C(C)(C)C)cc1-c1ccccc1)c1cc4oc5ccccc5c4cc1B3c1ccc(-c3ccccc3)cc1N2c1cc2c(cc1C)C(C)(C)CCC2(C)C ; Cc1cc2c(cc1N1c3ccc(-c4ccccc4)cc3B3c4c1cc(-c1c(C)cccc1C)cc4N(c1ccc(C(C)(C)C)cc1-c1ccccc1)c1ccc4c(oc5ccccc54)c13)C(C)(C)CCC2(C)C]

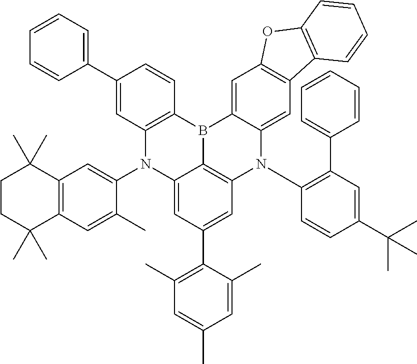 [SMILES: Cc1cc(C)c(-c2cc3c4c(c2)N(c2ccc(C(C)(C)C)cc2-c2ccccc2)c2cc5c(cc2B4c2ccc(-c4ccccc4)cc2N3c2cc3c(cc2C)C(C)(C)CCC3(C)C)oc2ccccc25)c(C)c1]

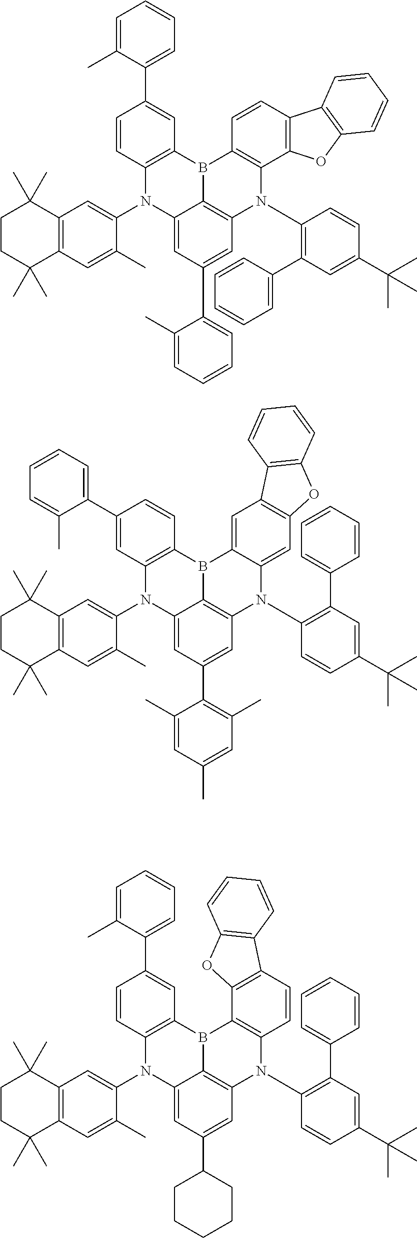 [SMILES: Cc1ccccc1-c1ccc2c(c1)B1c3ccc4c(oc5ccccc54)c3N(c3ccc(C(C)(C)C)cc3-c3ccccc3)c3cc(-c4ccccc4C)cc(c31)N2c1cc2c(cc1C)C(C)(C)CCC2(C)C ; Cc1cc(C)c(-c2cc3c4c(c2)N(c2ccc(C(C)(C)C)cc2-c2ccccc2)c2cc5oc6ccccc6c5cc2B4c2ccc(-c4ccccc4C)cc2N3c2cc3c(cc2C)C(C)(C)CCC3(C)C)c(C)c1 ; Cc1ccccc1-c1ccc2c(c1)B1c3c(cc(C4CCCCC4)cc3N(c3ccc(C(C)(C)C)cc3-c3ccccc3)c3ccc4c(oc5ccccc54)c31)N2c1cc2c(cc1C)C(C)(C)CCC2(C)C]

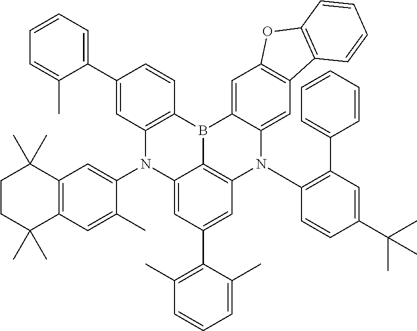 [SMILES: Cc1ccccc1-c1ccc2c(c1)N(c1cc3c(cc1C)C(C)(C)CCC3(C)C)c1cc(-c3c(C)cccc3C)cc3c1B2c1cc2oc4ccccc4c2cc1N3c1ccc(C(C)(C)C)cc1-c1ccccc1]

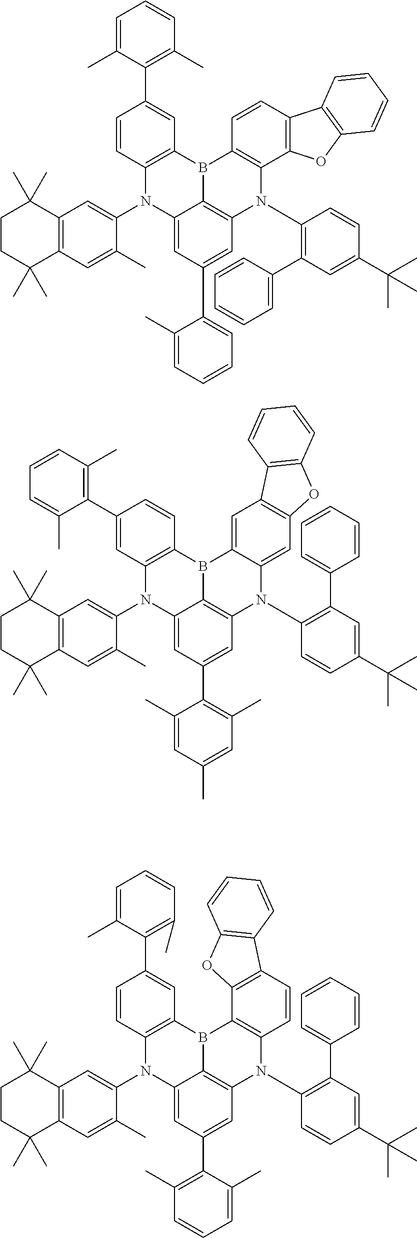 [SMILES: Cc1ccccc1-c1cc2c3c(c1)N(c1ccc(C(C)(C)C)cc1-c1ccccc1)c1c(ccc4c1oc1ccccc14)B3c1cc(-c3c(C)cccc3C)ccc1N2c1cc2c(cc1C)C(C)(C)CCC2(C)C ; Cc1cc(C)c(-c2cc3c4c(c2)N(c2ccc(C(C)(C)C)cc2-c2ccccc2)c2cc5oc6ccccc6c5cc2B4c2ccc(-c4c(C)cccc4C)cc2N3c2cc3c(cc2C)C(C)(C)CCC3(C)C)c(C)c1 ; Cc1cc2c(cc1N1c3ccc(-c4c(C)cccc4C)cc3B3c4c1cc(-c1c(C)cccc1C)cc4N(c1ccc(C(C)(C)C)cc1-c1ccccc1)c1ccc4c(oc5ccccc54)c13)C(C)(C)CCC2(C)C]

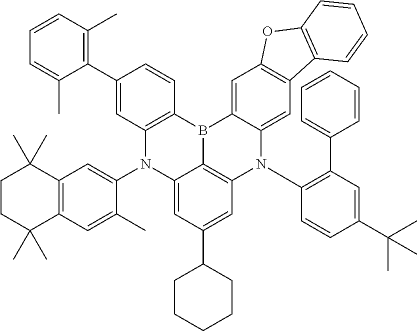 [SMILES: Cc1cc2c(cc1N1c3cc(-c4c(C)cccc4C)ccc3B3c4cc5oc6ccccc6c5cc4N(c4ccc(C(C)(C)C)cc4-c4ccccc4)c4cc(C5CCCCC5)cc1c43)C(C)(C)CCC2(C)C]

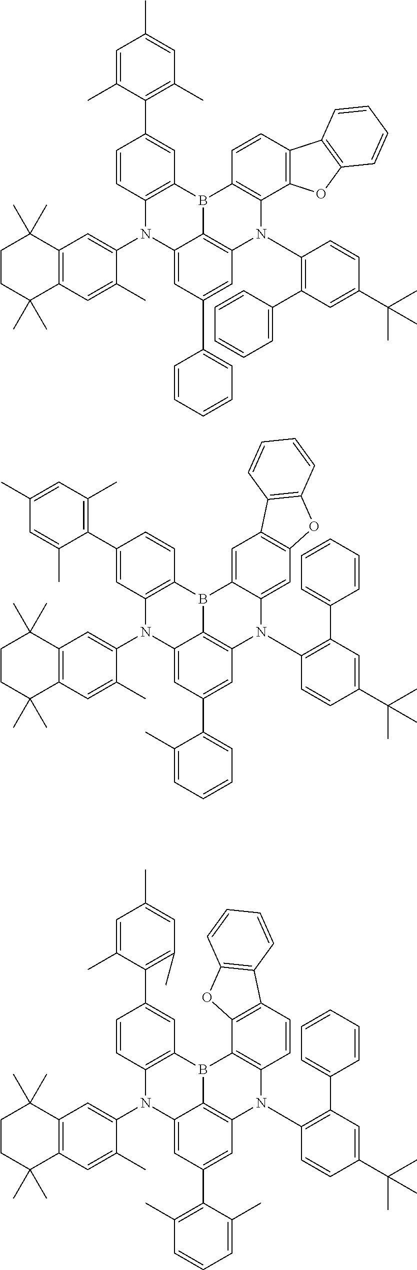 [SMILES: Cc1cc(C)c(-c2ccc3c(c2)B2c4ccc5c(oc6ccccc65)c4N(c4ccc(C(C)(C)C)cc4-c4ccccc4)c4cc(-c5ccccc5)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(-c4ccccc4C)cc4c2B3c2cc3c(cc2N4c2ccc(C(C)(C)C)cc2-c2ccccc2)oc2ccccc23)c(C)c1 ; Cc1cc(C)c(-c2ccc3c(c2)B2c4c(cc(-c5c(C)cccc5C)cc4N(c4ccc(C(C)(C)C)cc4-c4ccccc4)c4ccc5c(oc6ccccc65)c42)N3c2cc3c(cc2C)C(C)(C)CCC3(C)C)c(C)c1]

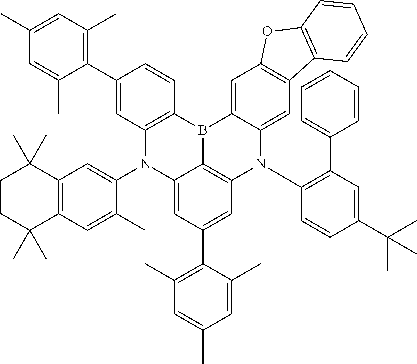 [SMILES: Cc1cc(C)c(-c2ccc3c(c2)N(c2cc4c(cc2C)C(C)(C)CCC4(C)C)c2cc(-c4c(C)cc(C)cc4C)cc4c2B3c2cc3oc5ccccc5c3cc2N4c2ccc(C(C)(C)C)cc2-c2ccccc2)c(C)c1]

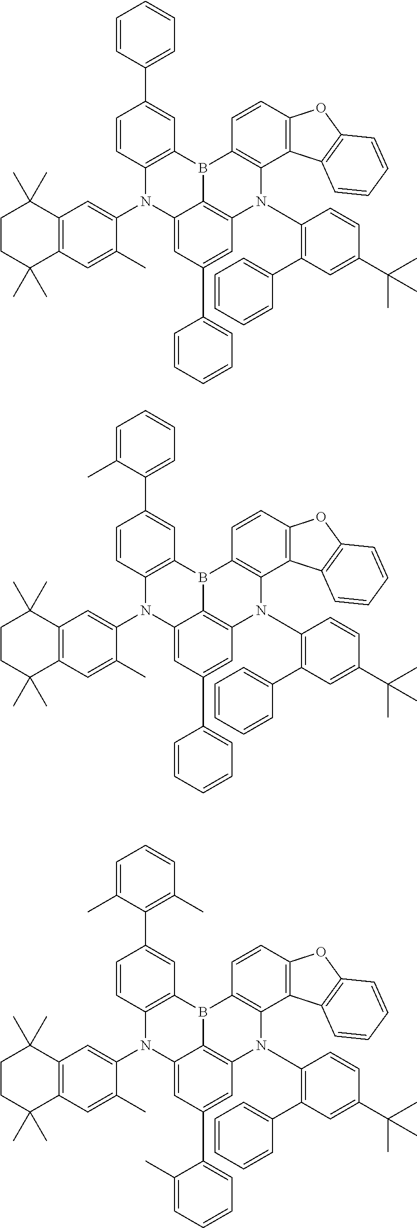 [SMILES: Cc1cc2c(cc1N1c3ccc(-c4ccccc4)cc3B3c4ccc5oc6ccccc6c5c4N(c4ccc(C(C)(C)C)cc4-c4ccccc4)c4cc(-c5ccccc5)cc1c43)C(C)(C)CCC2(C)C ; Cc1ccccc1-c1ccc2c(c1)B1c3ccc4oc5ccccc5c4c3N(c3ccc(C(C)(C)C)cc3-c3ccccc3)c3cc(-c4ccccc4)cc(c31)N2c1cc2c(cc1C)C(C)(C)CCC2(C)C ; Cc1ccccc1-c1cc2c3c(c1)N(c1ccc(C(C)(C)C)cc1-c1ccccc1)c1c(ccc4oc5ccccc5c14)B3c1cc(-c3c(C)cccc3C)ccc1N2c1cc2c(cc1C)C(C)(C)CCC2(C)C]

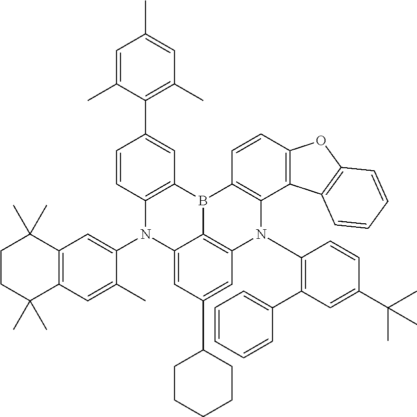 [SMILES: Cc1cc(C)c(-c2ccc3c(c2)B2c4ccc5oc6ccccc6c5c4N(c4ccc(C(C)(C)C)cc4-c4ccccc4)c4cc(C5CCCCC5)cc(c42)N3c2cc3c(cc2C)C(C)(C)CCC3(C)C)c(C)c1]

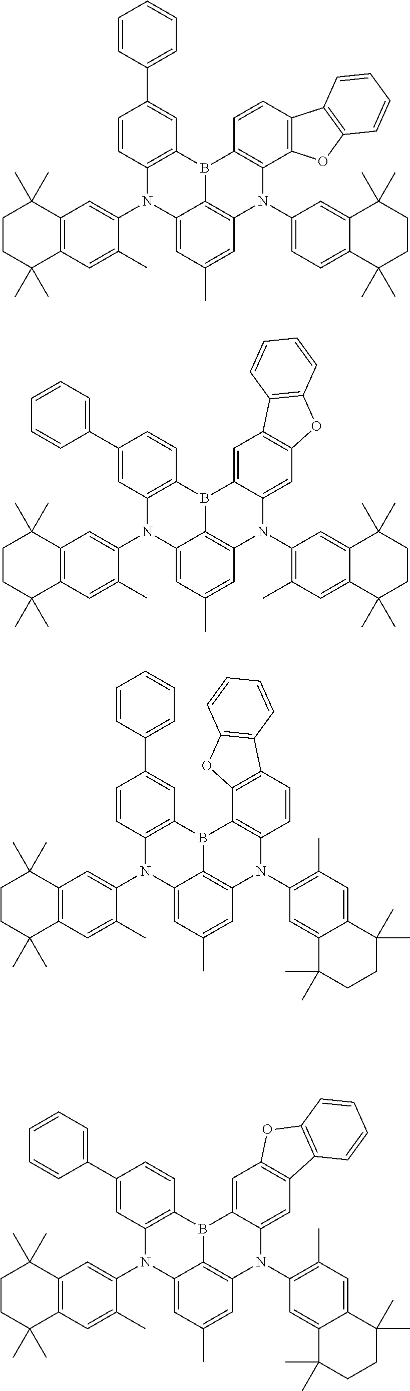 [SMILES: Cc1cc2c3c(c1)N(c1ccc4c(c1)C(C)(C)CCC4(C)C)c1c(ccc4c1oc1ccccc14)B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4oc5ccccc5c4cc1B3c1ccc(-c3ccccc3)cc1N2c1cc2c(cc1C)C(C)(C)CCC2(C)C ; Cc1cc2c3c(c1)N(c1cc4c(cc1C)C(C)(C)CCC4(C)C)c1ccc4c(oc5ccccc54)c1B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3ccccc3)cc1N2c1cc2c(cc1C)C(C)(C)CCC2(C)C)oc1ccccc14]

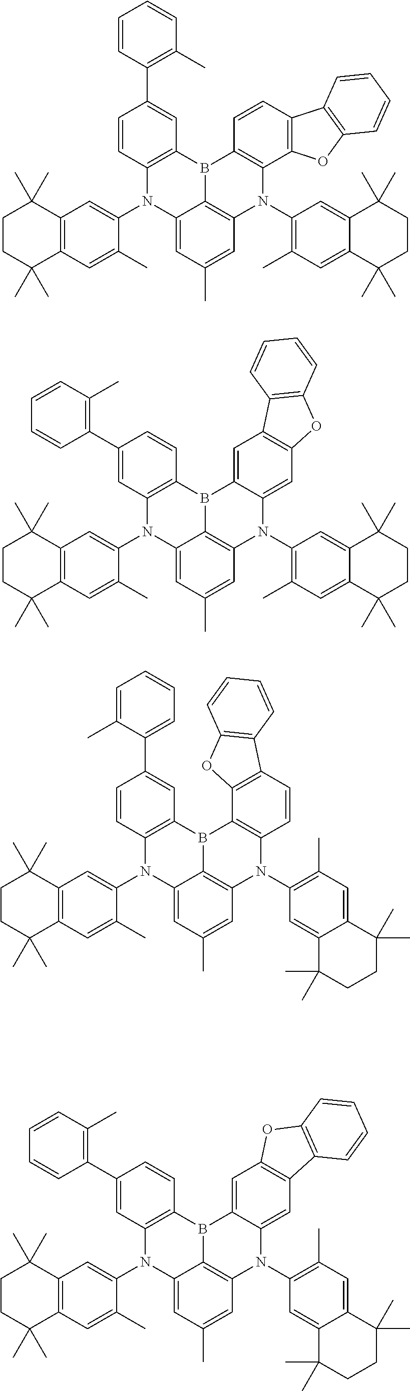 [SMILES: Cc1cc2c3c(c1)N(c1cc4c(cc1C)C(C)(C)CCC4(C)C)c1c(ccc4c1oc1ccccc14)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4oc5ccccc5c4cc1B3c1ccc(-c3ccccc3C)cc1N2c1cc2c(cc1C)C(C)(C)CCC2(C)C ; Cc1cc2c3c(c1)N(c1cc4c(cc1C)C(C)(C)CCC4(C)C)c1ccc4c(oc5ccccc54)c1B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3ccccc3C)cc1N2c1cc2c(cc1C)C(C)(C)CCC2(C)C)oc1ccccc14]

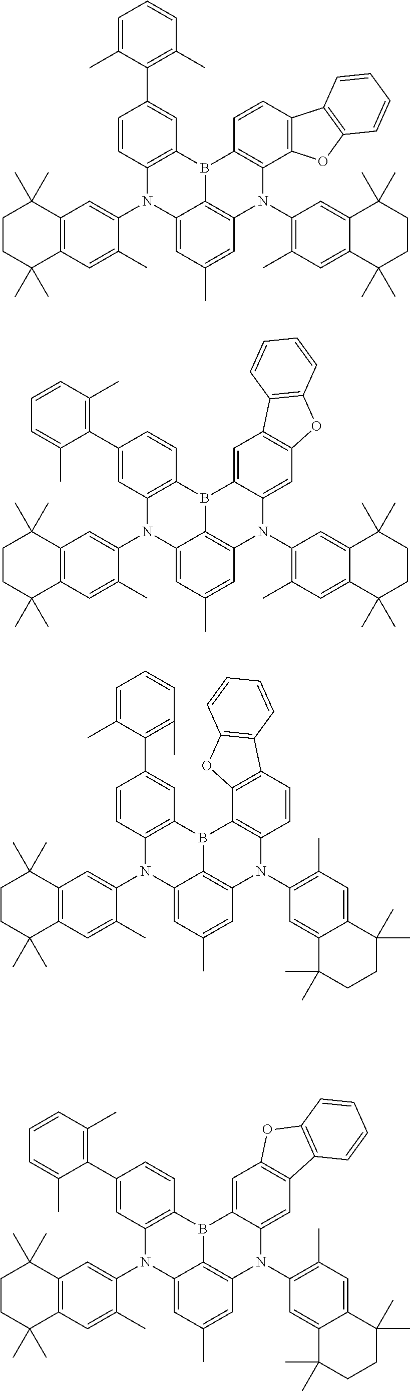 [SMILES: Cc1cc2c3c(c1)N(c1cc4c(cc1C)C(C)(C)CCC4(C)C)c1c(ccc4c1oc1ccccc14)B3c1cc(-c3c(C)cccc3C)ccc1N2c1cc2c(cc1C)C(C)(C)CCC2(C)C ; Cc1cc2c3c(c1)N(c1cc4c(cc1C)C(C)(C)CCC4(C)C)c1cc4oc5ccccc5c4cc1B3c1ccc(-c3c(C)cccc3C)cc1N2c1cc2c(cc1C)C(C)(C)CCC2(C)C ; Cc1cc2c3c(c1)N(c1cc4c(cc1C)C(C)(C)CCC4(C)C)c1ccc4c(oc5ccccc54)c1B3c1cc(-c3c(C)cccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3c(C)cccc3C)cc1N2c1cc2c(cc1C)C(C)(C)CCC2(C)C)oc1ccccc14]

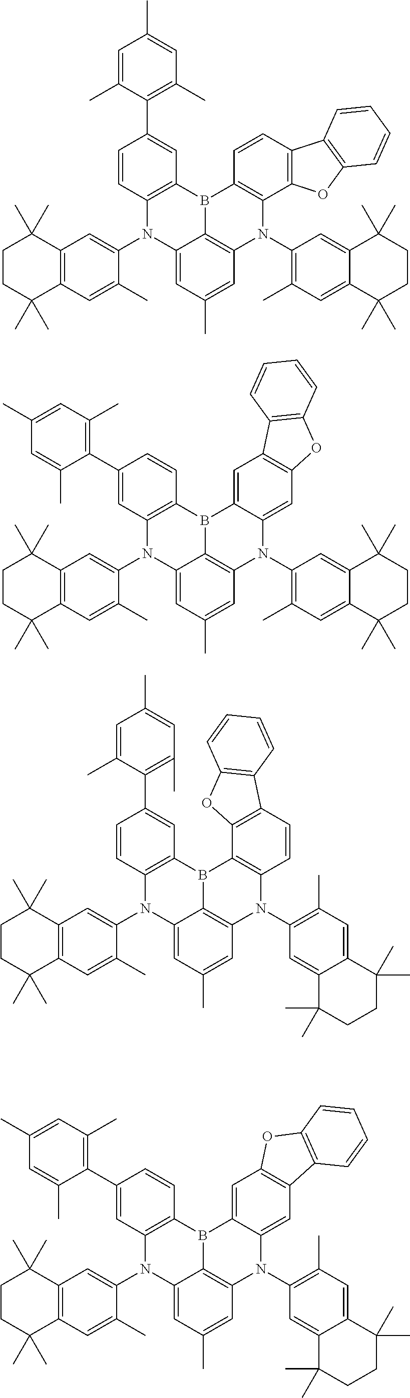

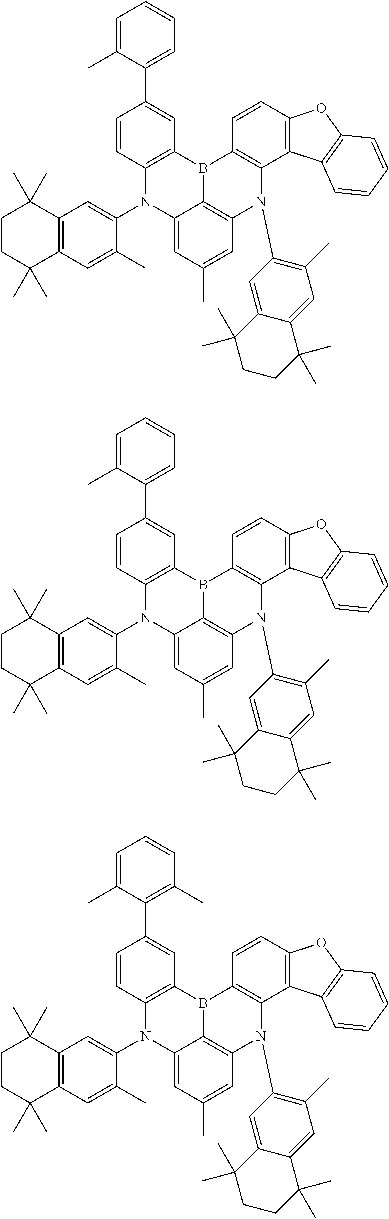 [SMILES: Cc1cc2c3c(c1)N(c1cc4c(cc1C)C(C)(C)CCC4(C)C)c1c(ccc4oc5ccccc5c14)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1c(ccc4oc5ccccc5c14)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1c(ccc4oc5ccccc5c14)B3c1cc(-c3c(C)cccc3C)ccc1N2c1cc2c(cc1C)C(C)(C)CCC2(C)C]

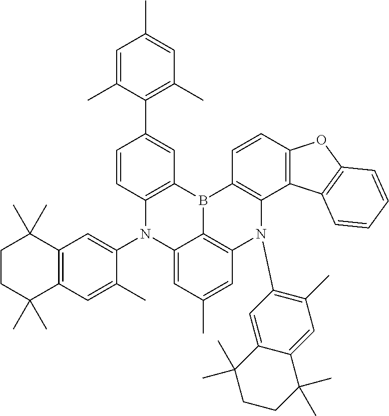 [SMILES: Cc1cc(C)c(-c2ccc3c(c2)B2c4ccc5oc6ccccc6c5c4N(c4cc5c(cc4C)C(C)(C)CCC5(C)C)c4cc(C)cc(c42)N3c2cc3c(cc2C)C(C)(C)CCC3(C)C)c(C)c1]

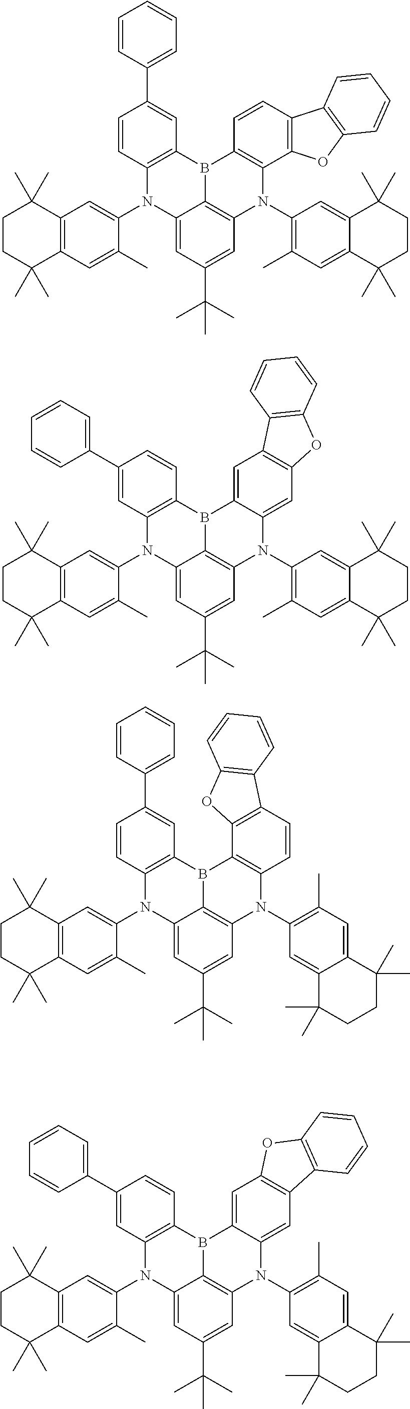

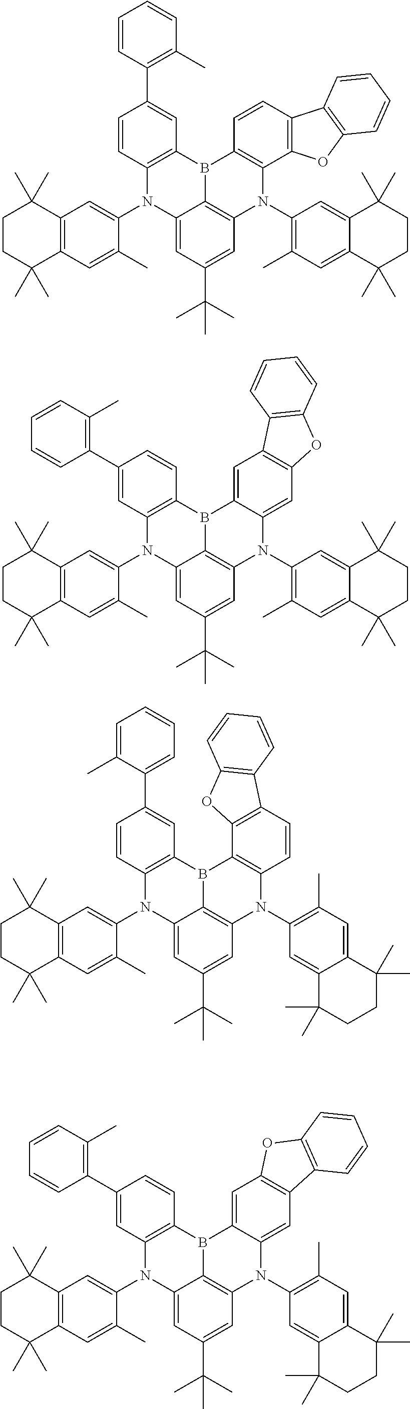

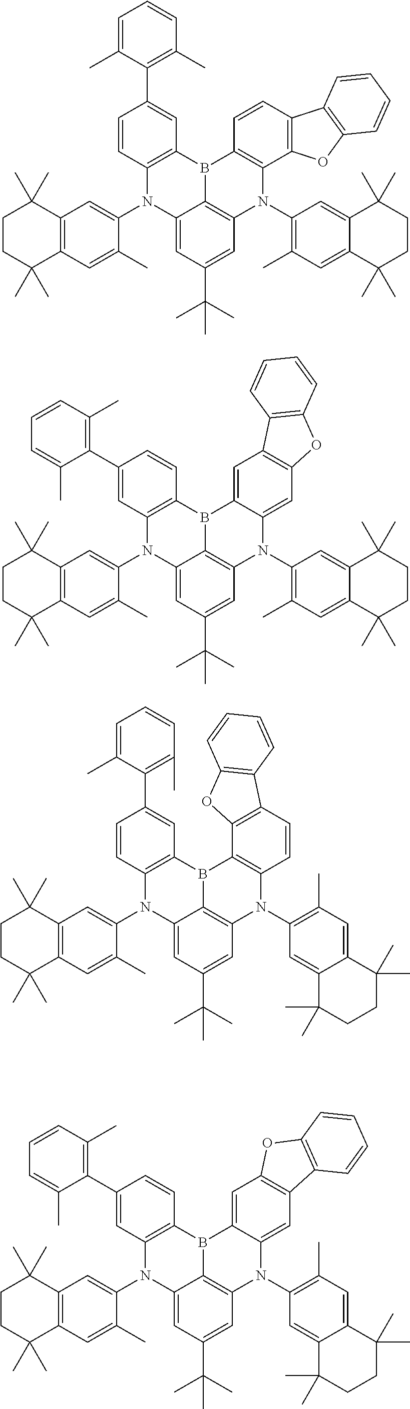

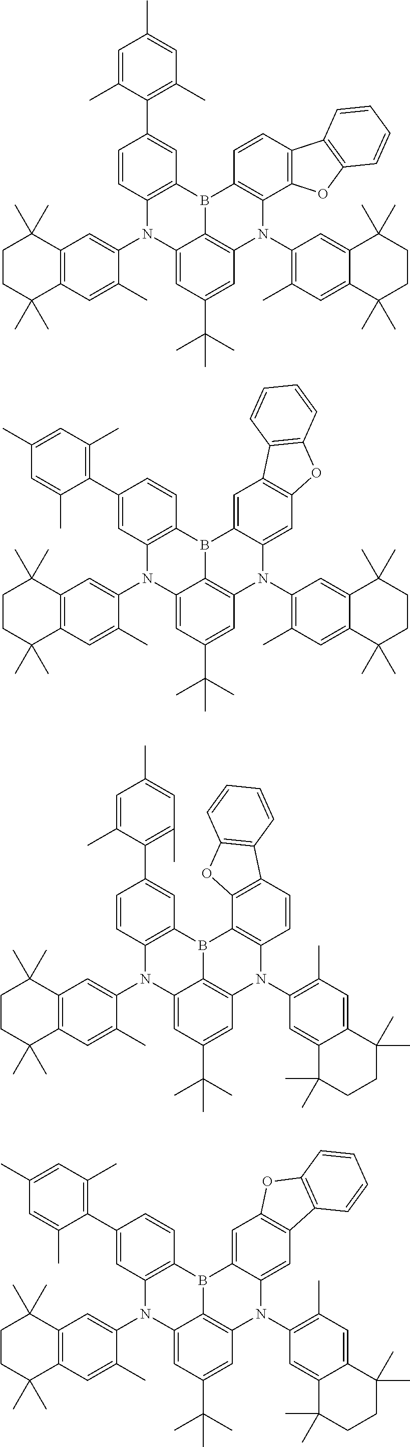

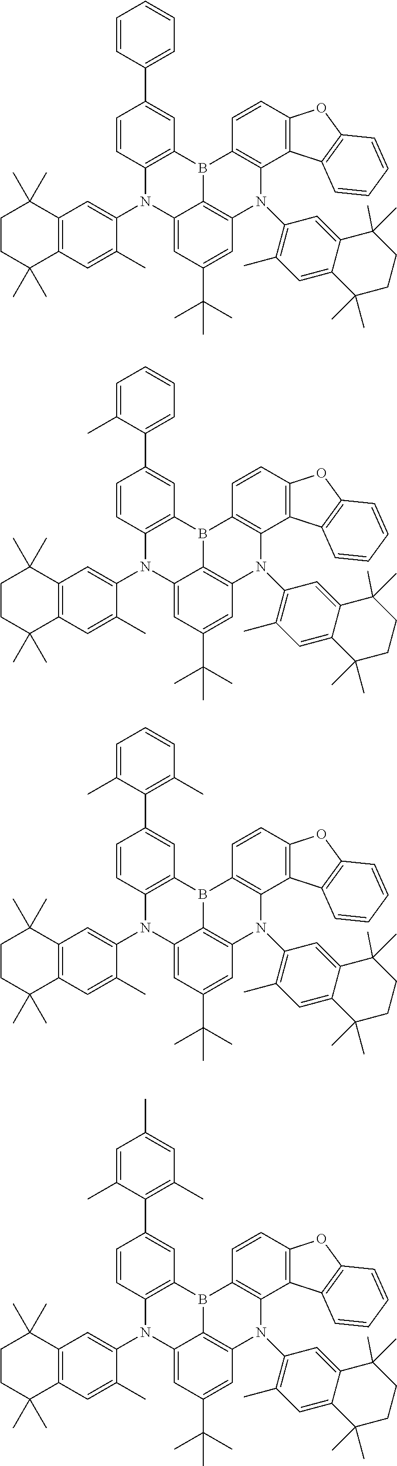

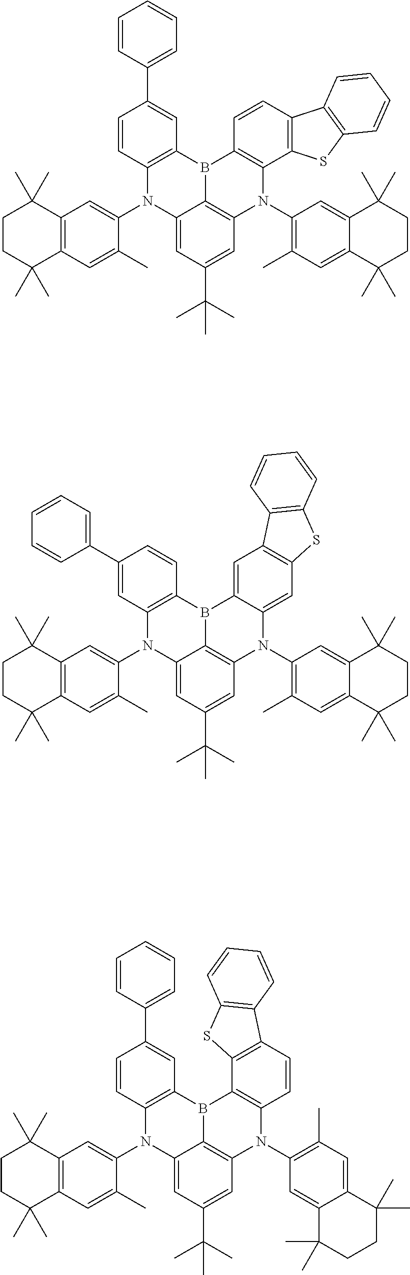 [SMILES: Cc1cc2c(cc1N1c3ccc(-c4ccccc4)cc3B3c4ccc5c(sc6ccccc65)c4N(c4cc5c(cc4C)C(C)(C)CCC5(C)C)c4cc(C(C)(C)C)cc1c43)C(C)(C)CCC2(C)C ; Cc1cc2c(cc1N1c3cc(-c4ccccc4)ccc3B3c4cc5c(cc4N(c4cc6c(cc4C)C(C)(C)CCC6(C)C)c4cc(C(C)(C)C)cc1c43)sc1ccccc15)C(C)(C)CCC2(C)C ; Cc1cc2c(cc1N1c3ccc(-c4ccccc4)cc3B3c4c1cc(C(C)(C)C)cc4N(c1cc4c(cc1C)C(C)(C)CCC4(C)C)c1ccc4c(sc5ccccc54)c13)C(C)(C)CCC2(C)C]

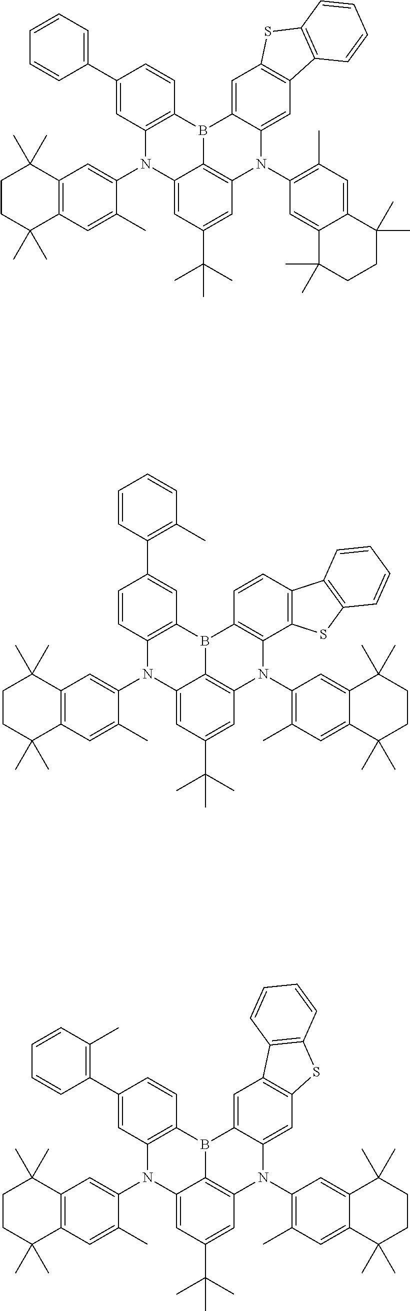 [SMILES: Cc1cc2c(cc1N1c3cc(-c4ccccc4)ccc3B3c4cc5sc6ccccc6c5cc4N(c4cc5c(cc4C)C(C)(C)CCC5(C)C)c4cc(C(C)(C)C)cc1c43)C(C)(C)CCC2(C)C ; Cc1ccccc1-c1ccc2c(c1)B1c3ccc4c(sc5ccccc54)c3N(c3cc4c(cc3C)C(C)(C)CCC4(C)C)c3cc(C(C)(C)C)cc(c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(C(C)(C)C)cc3c1B2c1cc2c(cc1N3c1cc3c(cc1C)C(C)(C)CCC3(C)C)sc1ccccc12]

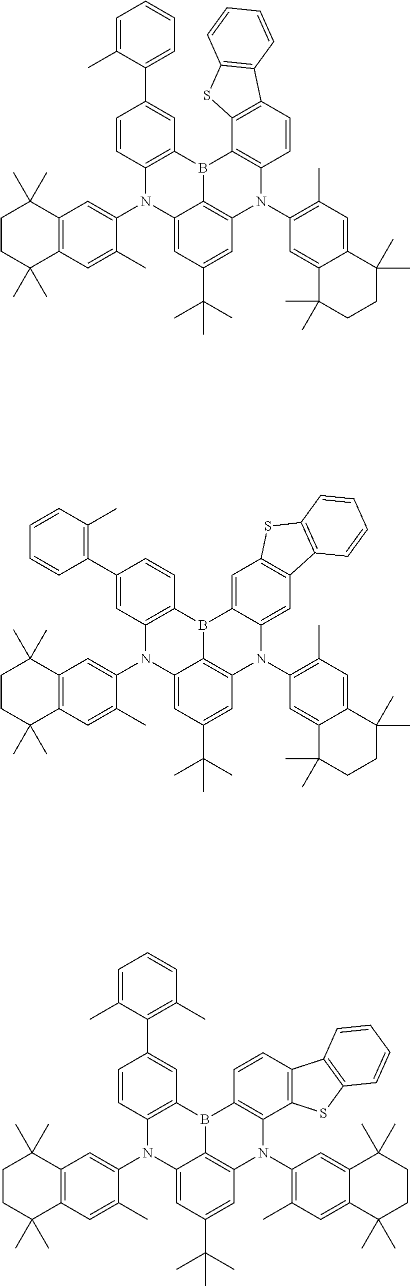 [SMILES: Cc1ccccc1-c1ccc2c(c1)B1c3c(cc(C(C)(C)C)cc3N(c3cc4c(cc3C)C(C)(C)CCC4(C)C)c3ccc4c(sc5ccccc54)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(C(C)(C)C)cc3c1B2c1cc2sc4ccccc4c2cc1N3c1cc2c(cc1C)C(C)(C)CCC2(C)C ; Cc1cc2c(cc1N1c3ccc(-c4c(C)cccc4C)cc3B3c4ccc5c(sc6ccccc65)c4N(c4cc5c(cc4C)C(C)(C)CCC5(C)C)c4cc(C(C)(C)C)cc1c43)C(C)(C)CCC2(C)C]

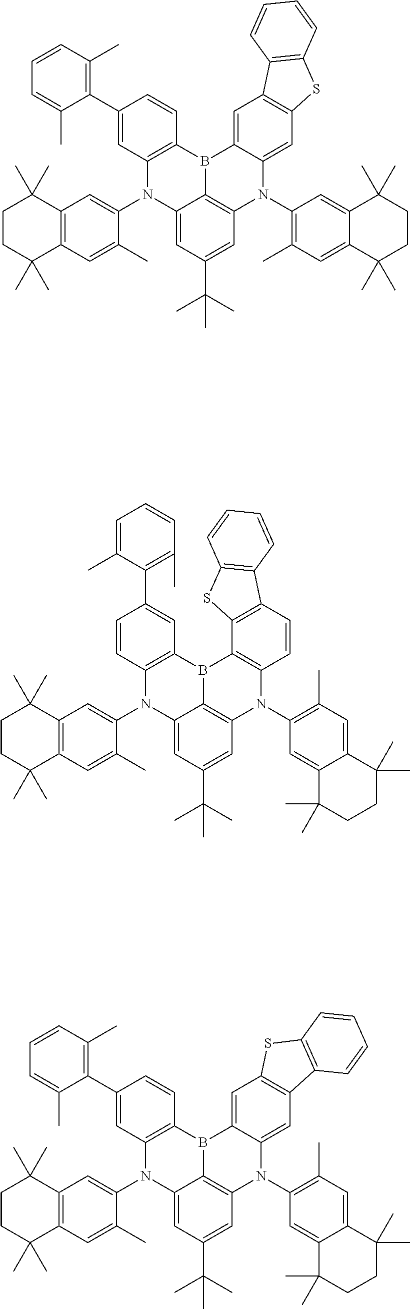 [SMILES: Cc1cc2c(cc1N1c3cc(-c4c(C)cccc4C)ccc3B3c4cc5c(cc4N(c4cc6c(cc4C)C(C)(C)CCC6(C)C)c4cc(C(C)(C)C)cc1c43)sc1ccccc15)C(C)(C)CCC2(C)C ; Cc1cc2c(cc1N1c3ccc(-c4c(C)cccc4C)cc3B3c4c1cc(C(C)(C)C)cc4N(c1cc4c(cc1C)C(C)(C)CCC4(C)C)c1ccc4c(sc5ccccc54)c13)C(C)(C)CCC2(C)C ; Cc1cc2c(cc1N1c3cc(-c4c(C)cccc4C)ccc3B3c4cc5sc6ccccc6c5cc4N(c4cc5c(cc4C)C(C)(C)CCC5(C)C)c4cc(C(C)(C)C)cc1c43)C(C)(C)CCC2(C)C]

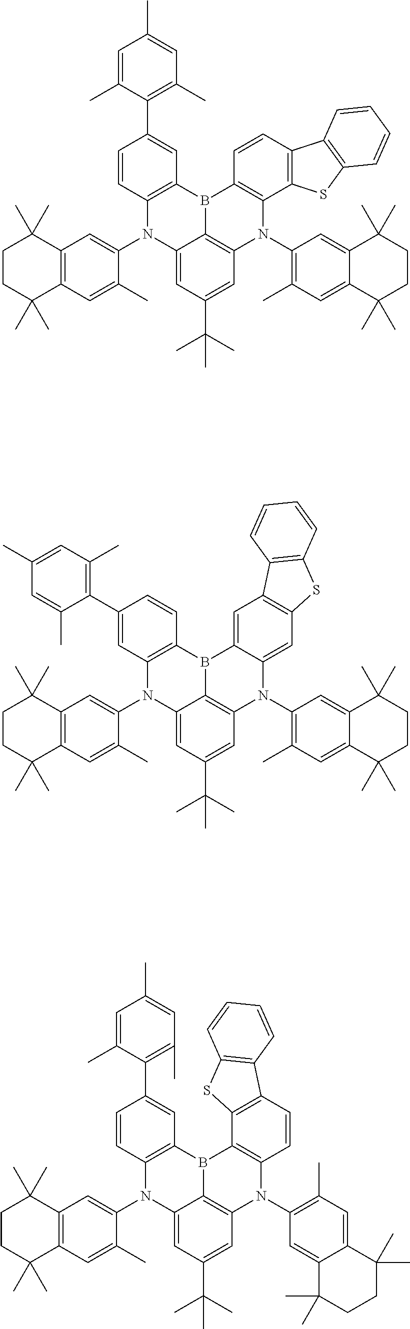 [SMILES: Cc1cc(C)c(-c2ccc3c(c2)B2c4ccc5c(sc6ccccc65)c4N(c4cc5c(cc4C)C(C)(C)CCC5(C)C)c4cc(C(C)(C)C)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(C(C)(C)C)cc4c2B3c2cc3c(cc2N4c2cc4c(cc2C)C(C)(C)CCC4(C)C)sc2ccccc23)c(C)c1 ; Cc1cc(C)c(-c2ccc3c(c2)B2c4c(cc(C(C)(C)C)cc4N(c4cc5c(cc4C)C(C)(C)CCC5(C)C)c4ccc5c(sc6ccccc65)c42)N3c2cc3c(cc2C)C(C)(C)CCC3(C)C)c(C)c1]

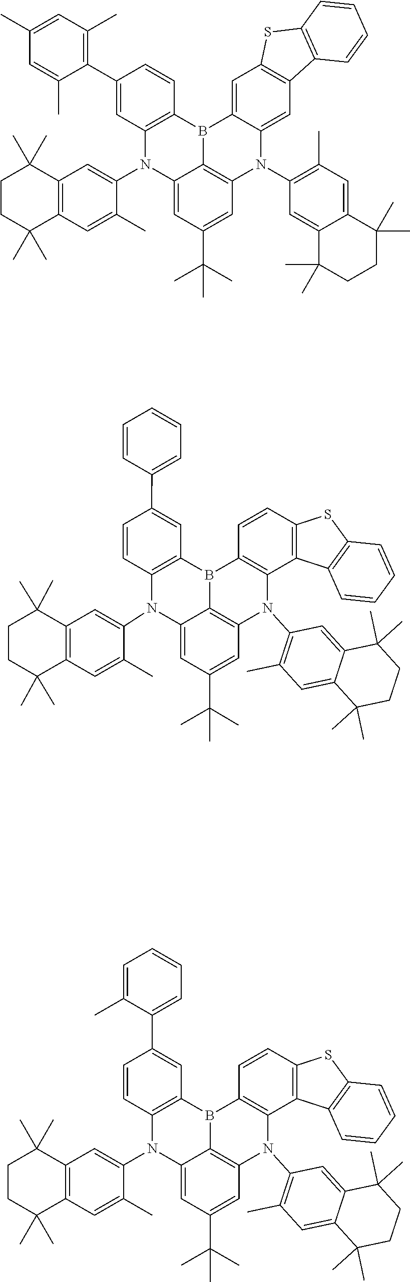

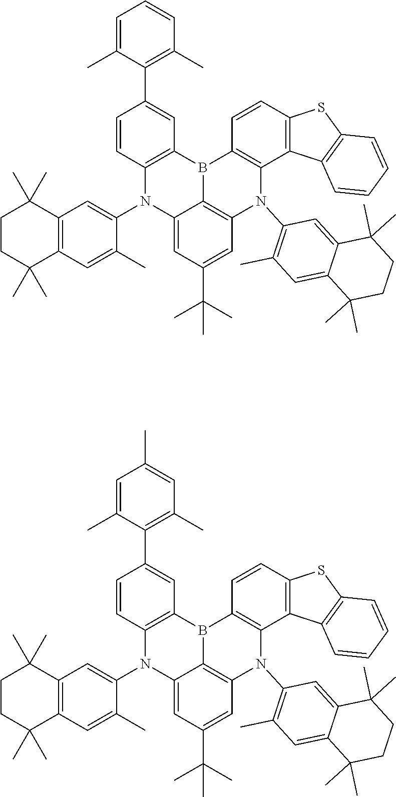 [SMILES: Cc1cc2c(cc1N1c3ccc(-c4c(C)cccc4C)cc3B3c4ccc5sc6ccccc6c5c4N(c4cc5c(cc4C)C(C)(C)CCC5(C)C)c4cc(C(C)(C)C)cc1c43)C(C)(C)CCC2(C)C ; Cc1cc(C)c(-c2ccc3c(c2)B2c4ccc5sc6ccccc6c5c4N(c4cc5c(cc4C)C(C)(C)CCC5(C)C)c4cc(C(C)(C)C)cc(c42)N3c2cc3c(cc2C)C(C)(C)CCC3(C)C)c(C)c1]

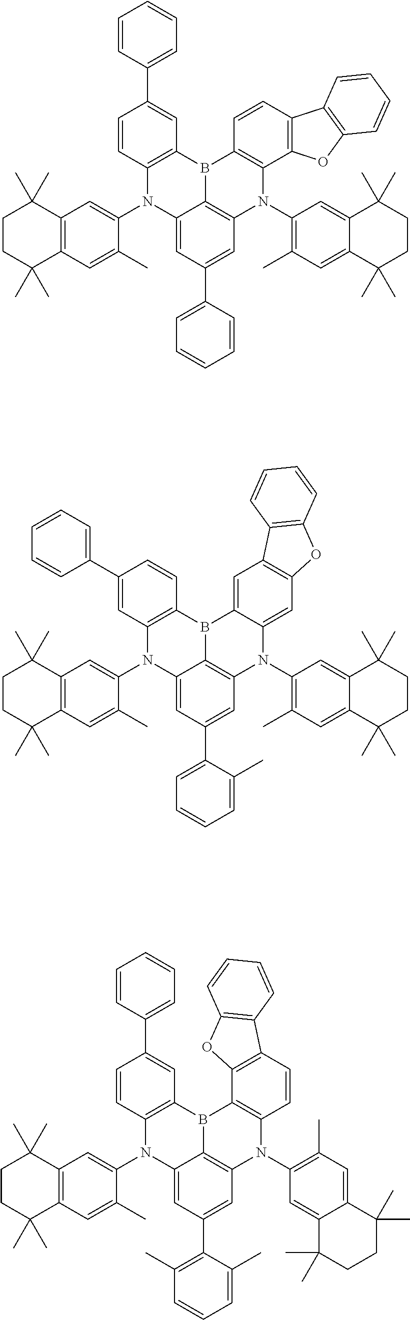 [SMILES: Cc1cc2c(cc1N1c3ccc(-c4ccccc4)cc3B3c4ccc5c(oc6ccccc65)c4N(c4cc5c(cc4C)C(C)(C)CCC5(C)C)c4cc(-c5ccccc5)cc1c43)C(C)(C)CCC2(C)C ; Cc1ccccc1-c1cc2c3c(c1)N(c1cc4c(cc1C)C(C)(C)CCC4(C)C)c1cc4oc5ccccc5c4cc1B3c1ccc(-c3ccccc3)cc1N2c1cc2c(cc1C)C(C)(C)CCC2(C)C ; Cc1cc2c(cc1N1c3ccc(-c4ccccc4)cc3B3c4c1cc(-c1c(C)cccc1C)cc4N(c1cc4c(cc1C)C(C)(C)CCC4(C)C)c1ccc4c(oc5ccccc54)c13)C(C)(C)CCC2(C)C]

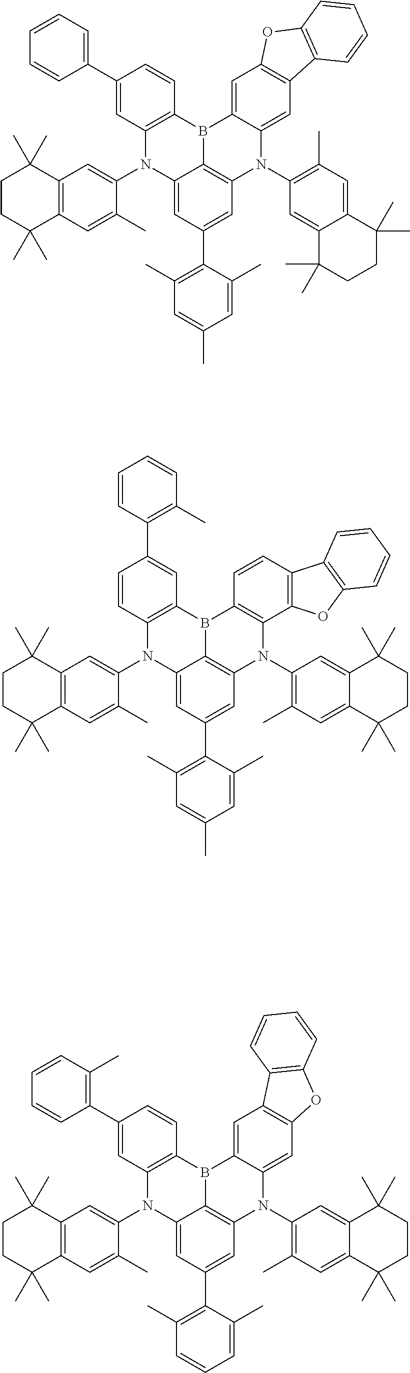 [SMILES: Cc1cc(C)c(-c2cc3c4c(c2)N(c2cc5c(cc2C)C(C)(C)CCC5(C)C)c2cc5c(cc2B4c2ccc(-c4ccccc4)cc2N3c2cc3c(cc2C)C(C)(C)CCC3(C)C)oc2ccccc25)c(C)c1 ; Cc1cc(C)c(-c2cc3c4c(c2)N(c2cc5c(cc2C)C(C)(C)CCC5(C)C)c2c(ccc5c2oc2ccccc25)B4c2cc(-c4ccccc4C)ccc2N3c2cc3c(cc2C)C(C)(C)CCC3(C)C)c(C)c1 ; Cc1ccccc1-c1ccc2c(c1)N(c1cc3c(cc1C)C(C)(C)CCC3(C)C)c1cc(-c3c(C)cccc3C)cc3c1B2c1cc2c(cc1N3c1cc3c(cc1C)C(C)(C)CCC3(C)C)oc1ccccc12]

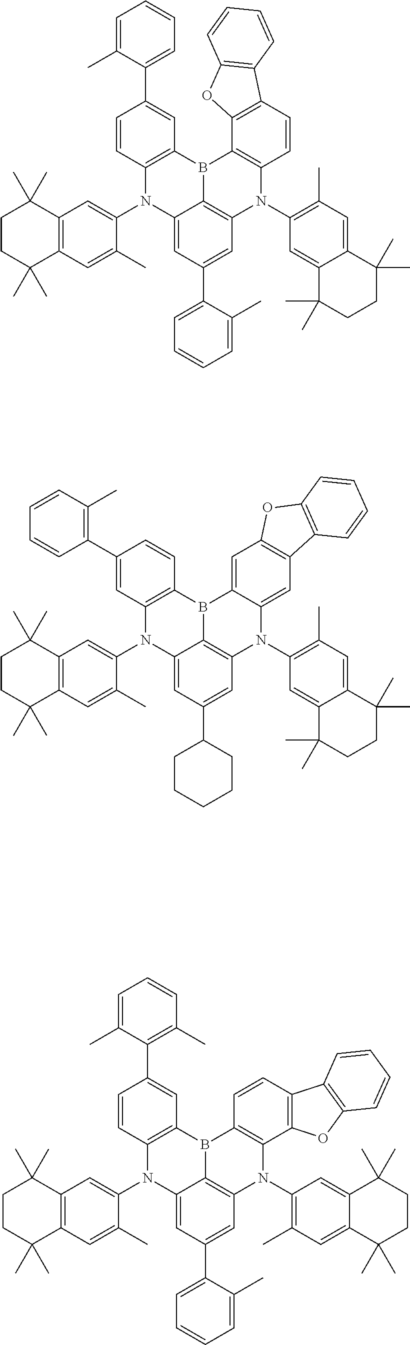 [SMILES: Cc1ccccc1-c1ccc2c(c1)B1c3c(cc(-c4ccccc4C)cc3N(c3cc4c(cc3C)C(C)(C)CCC4(C)C)c3ccc4c(oc5ccccc54)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(C3CCCCC3)cc3c1B2c1cc2oc4ccccc4c2cc1N3c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1oc1ccccc14)B3c1cc(-c3c(C)cccc3C)ccc1N2c1cc2c(cc1C)C(C)(C)CCC2(C)C]

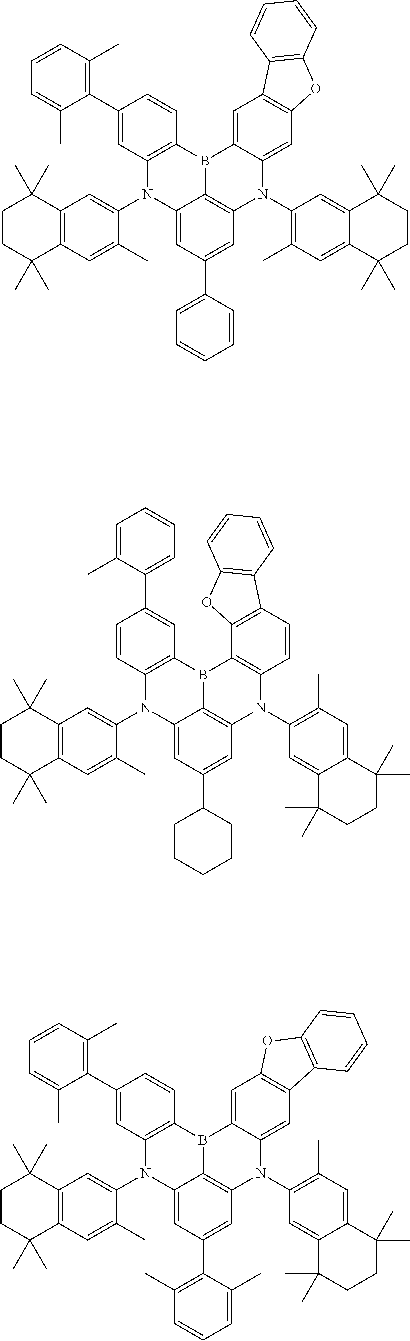 [SMILES: Cc1cc2c(cc1N1c3cc(-c4c(C)cccc4C)ccc3B3c4cc5c(cc4N(c4cc6c(cc4C)C(C)(C)CCC6(C)C)c4cc(-c6ccccc6)cc1c43)oc1ccccc15)C(C)(C)CCC2(C)C ; Cc1ccccc1-c1ccc2c(c1)B1c3c(cc(C4CCCCC4)cc3N(c3cc4c(cc3C)C(C)(C)CCC4(C)C)c3ccc4c(oc5ccccc54)c31)N2c1cc2c(cc1C)C(C)(C)CCC2(C)C ; Cc1cc2c(cc1N1c3cc(-c4c(C)cccc4C)ccc3B3c4cc5oc6ccccc6c5cc4N(c4cc5c(cc4C)C(C)(C)CCC5(C)C)c4cc(-c5c(C)cccc5C)cc1c43)C(C)(C)CCC2(C)C]

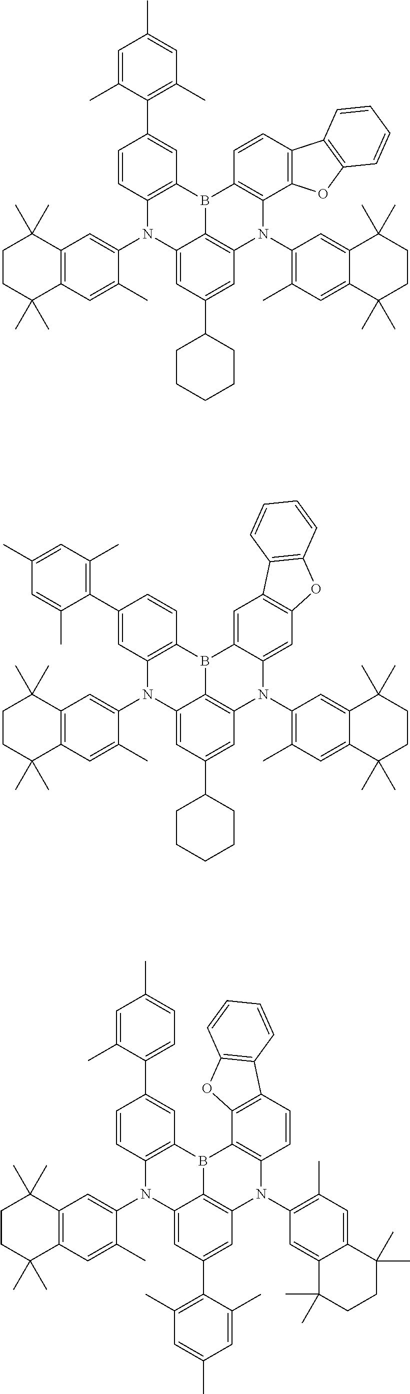 [SMILES: Cc1cc(C)c(-c2ccc3c(c2)B2c4ccc5c(oc6ccccc65)c4N(c4cc5c(cc4C)C(C)(C)CCC5(C)C)c4cc(C5CCCCC5)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(C4CCCCC4)cc4c2B3c2cc3c(cc2N4c2cc4c(cc2C)C(C)(C)CCC4(C)C)oc2ccccc23)c(C)c1 ; Cc1ccc(-c2ccc3c(c2)B2c4c(cc(-c5c(C)cc(C)cc5C)cc4N(c4cc5c(cc4C)C(C)(C)CCC5(C)C)c4ccc5c(oc6ccccc65)c42)N3c2cc3c(cc2C)C(C)(C)CCC3(C)C)c(C)c1]

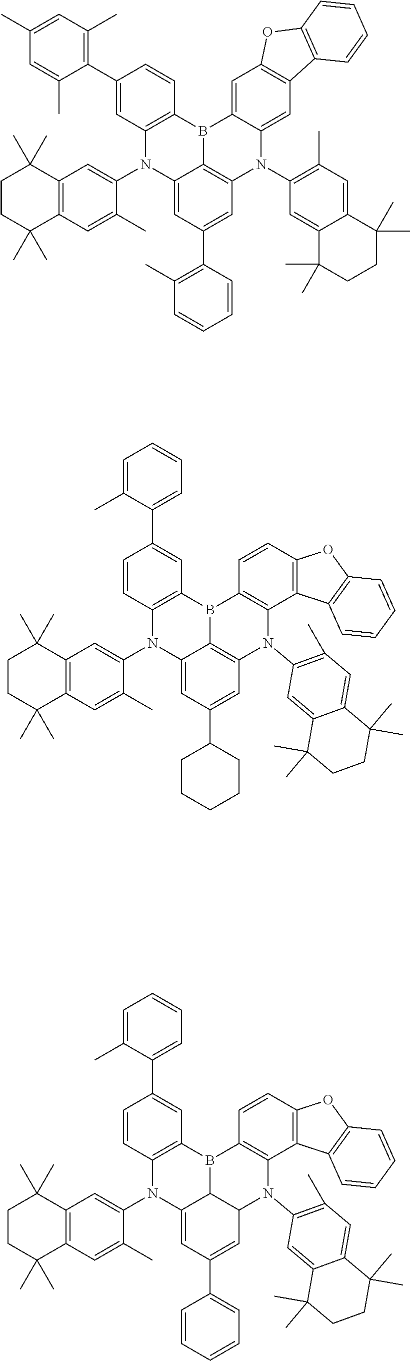

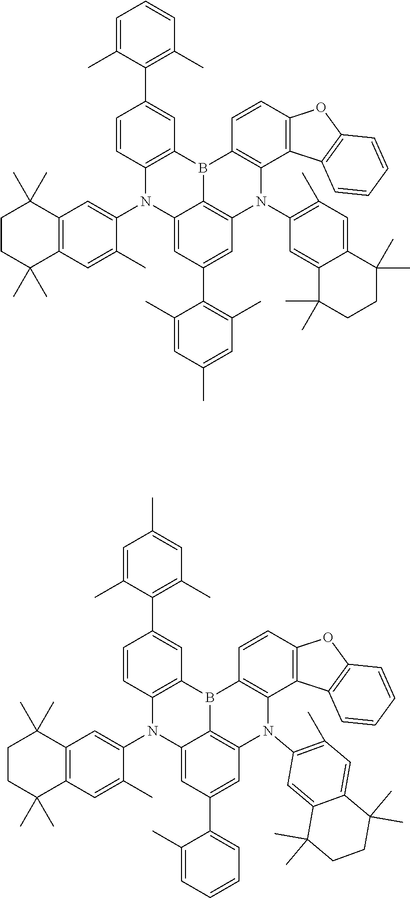 [SMILES: Cc1cc(C)c(-c2cc3c4c(c2)N(c2cc5c(cc2C)C(C)(C)CCC5(C)C)c2c(ccc5oc6ccccc6c25)B4c2cc(-c4c(C)cccc4C)ccc2N3c2cc3c(cc2C)C(C)(C)CCC3(C)C)c(C)c1 ; Cc1cc(C)c(-c2ccc3c(c2)B2c4ccc5oc6ccccc6c5c4N(c4cc5c(cc4C)C(C)(C)CCC5(C)C)c4cc(-c5ccccc5C)cc(c42)N3c2cc3c(cc2C)C(C)(C)CCC3(C)C)c(C)c1]

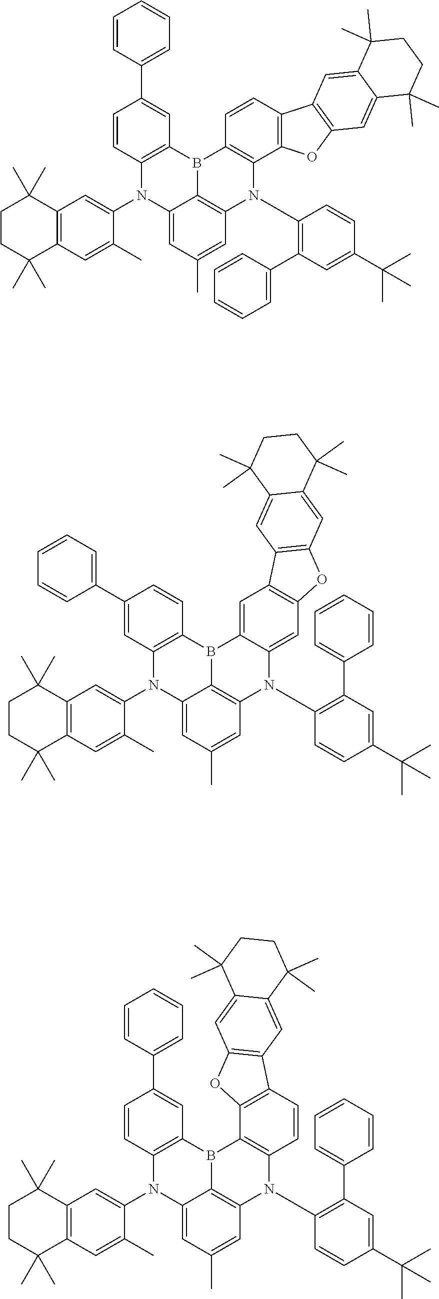 [SMILES: Cc1cc2c3c(c1)N(c1ccc(C(C)(C)C)cc1-c1ccccc1)c1c(ccc4c1oc1cc5c(cc14)C(C)(C)CCC5(C)C)B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1cc4oc5cc6c(cc5c4cc1B3c1ccc(-c3ccccc3)cc1N2c1cc2c(cc1C)C(C)(C)CCC2(C)C)C(C)(C)CCC6(C)C ; Cc1cc2c3c(c1)N(c1ccc(C(C)(C)C)cc1-c1ccccc1)c1ccc4c(oc5cc6c(cc54)C(C)(C)CCC6(C)C)c1B3c1cc(-c3ccccc3)ccc1N2c1cc2c(cc1C)C(C)(C)CCC2(C)C]

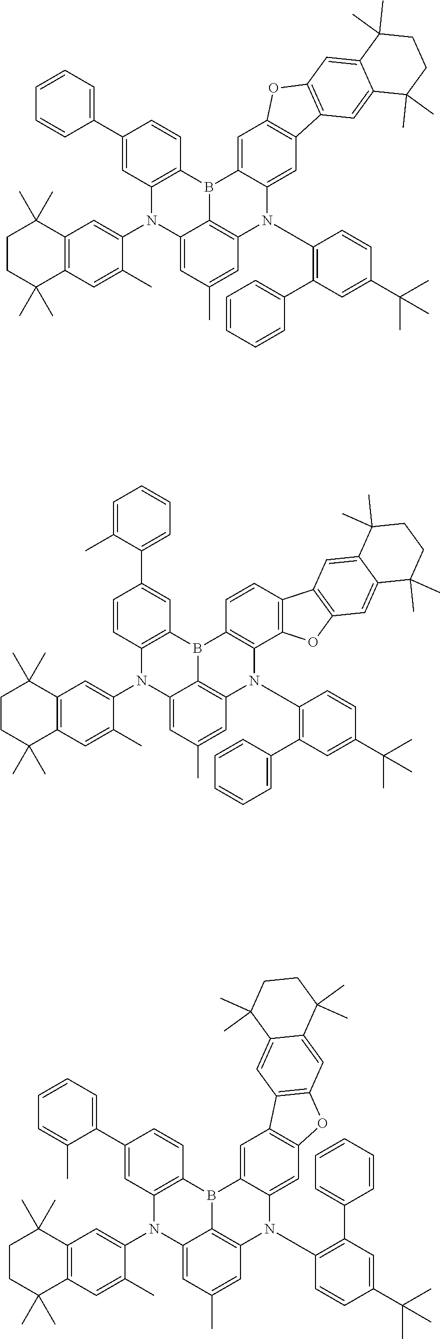 [SMILES: Cc1cc2c3c(c1)N(c1ccc(C(C)(C)C)cc1-c1ccccc1)c1cc4c(cc1B3c1ccc(-c3ccccc3)cc1N2c1cc2c(cc1C)C(C)(C)CCC2(C)C)oc1cc2c(cc14)C(C)(C)CCC2(C)C ; Cc1cc2c3c(c1)N(c1ccc(C(C)(C)C)cc1-c1ccccc1)c1c(ccc4c1oc1cc5c(cc14)C(C)(C)CCC5(C)C)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4oc5cc6c(cc5c4cc1B3c1ccc(-c3ccccc3C)cc1N2c1cc2c(cc1C)C(C)(C)CCC2(C)C)C(C)(C)CCC6(C)C]

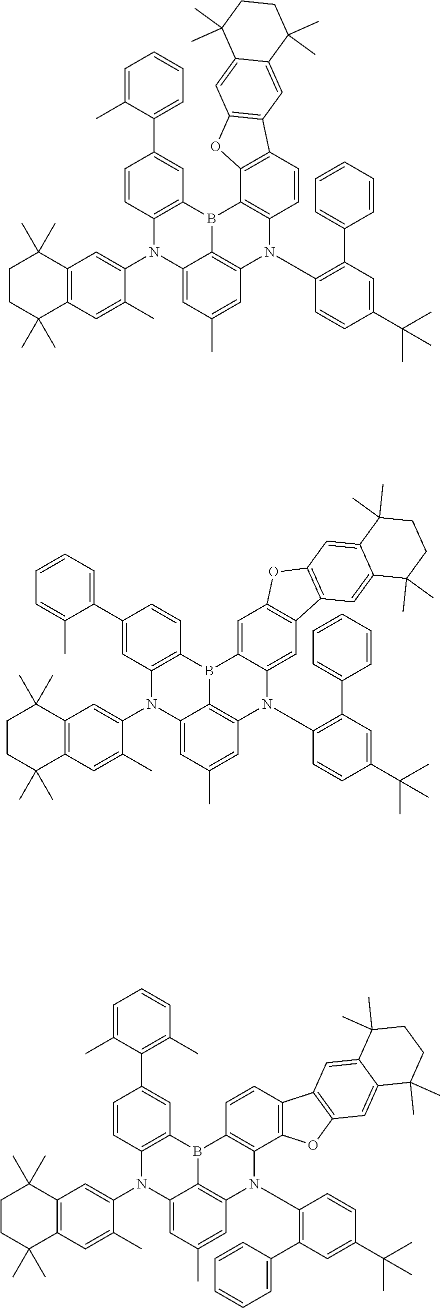 [SMILES: Cc1cc2c3c(c1)N(c1ccc(C(C)(C)C)cc1-c1ccccc1)c1ccc4c(oc5cc6c(cc54)C(C)(C)CCC6(C)C)c1B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3ccccc3C)cc1N2c1cc2c(cc1C)C(C)(C)CCC2(C)C)oc1cc2c(cc14)C(C)(C)CCC2(C)C ; Cc1cc2c3c(c1)N(c1ccc(C(C)(C)C)cc1-c1ccccc1)c1c(ccc4c1oc1cc5c(cc14)C(C)(C)CCC5(C)C)B3c1cc(-c3c(C)cccc3C)ccc1N2c1cc2c(cc1C)C(C)(C)CCC2(C)C]

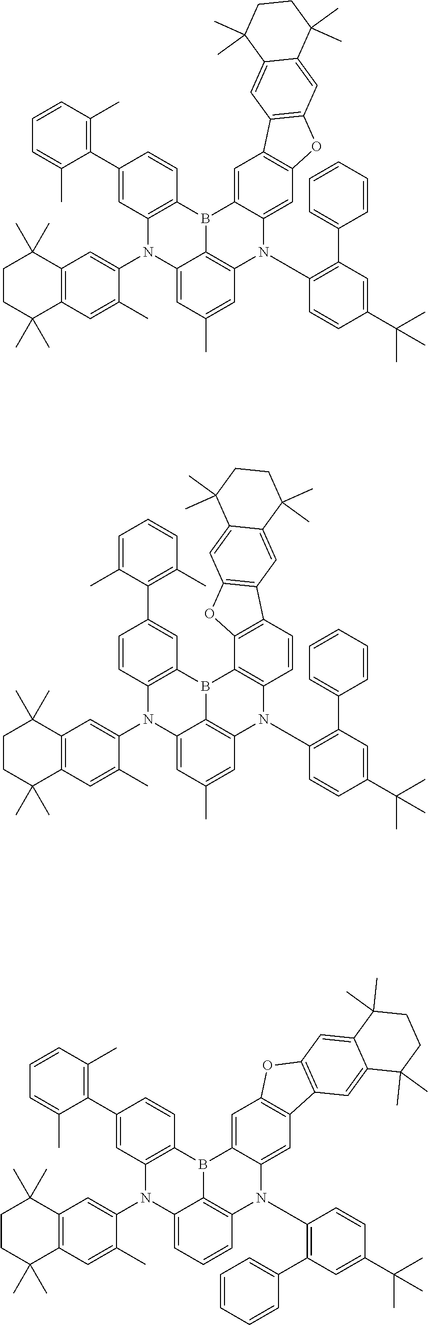 [SMILES: Cc1cc2c3c(c1)N(c1ccc(C(C)(C)C)cc1-c1ccccc1)c1cc4oc5cc6c(cc5c4cc1B3c1ccc(-c3c(C)cccc3C)cc1N2c1cc2c(cc1C)C(C)(C)CCC2(C)C)C(C)(C)CCC6(C)C ; Cc1cc2c3c(c1)N(c1ccc(C(C)(C)C)cc1-c1ccccc1)c1ccc4c(oc5cc6c(cc54)C(C)(C)CCC6(C)C)c1B3c1cc(-c3c(C)cccc3C)ccc1N2c1cc2c(cc1C)C(C)(C)CCC2(C)C ; Cc1cc2c(cc1N1c3cc(-c4c(C)cccc4C)ccc3B3c4cc5oc6cc7c(cc6c5cc4N(c4ccc(C(C)(C)C)cc4-c4ccccc4)c4cccc1c43)C(C)(C)CCC7(C)C)C(C)(C)CCC2(C)C]

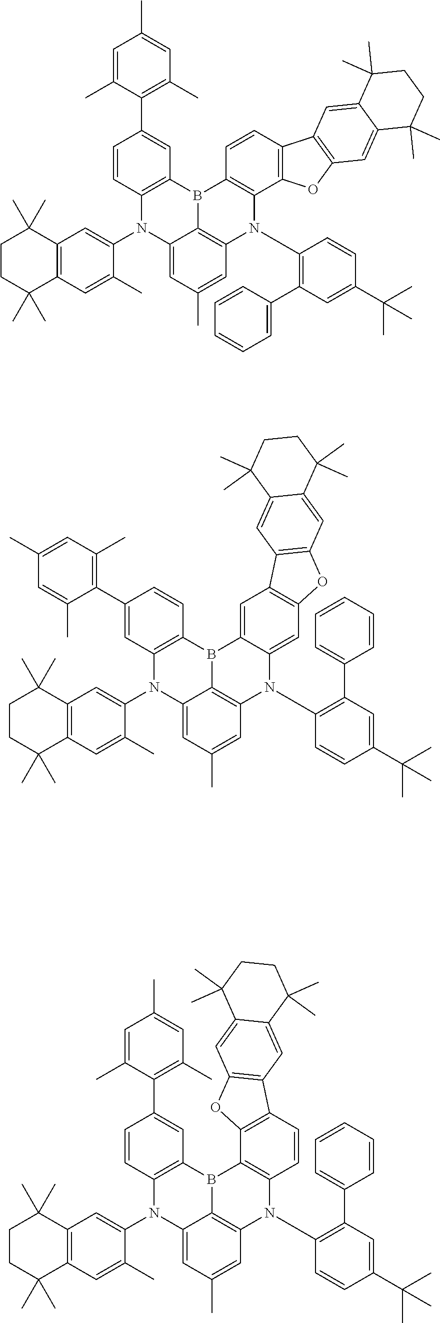

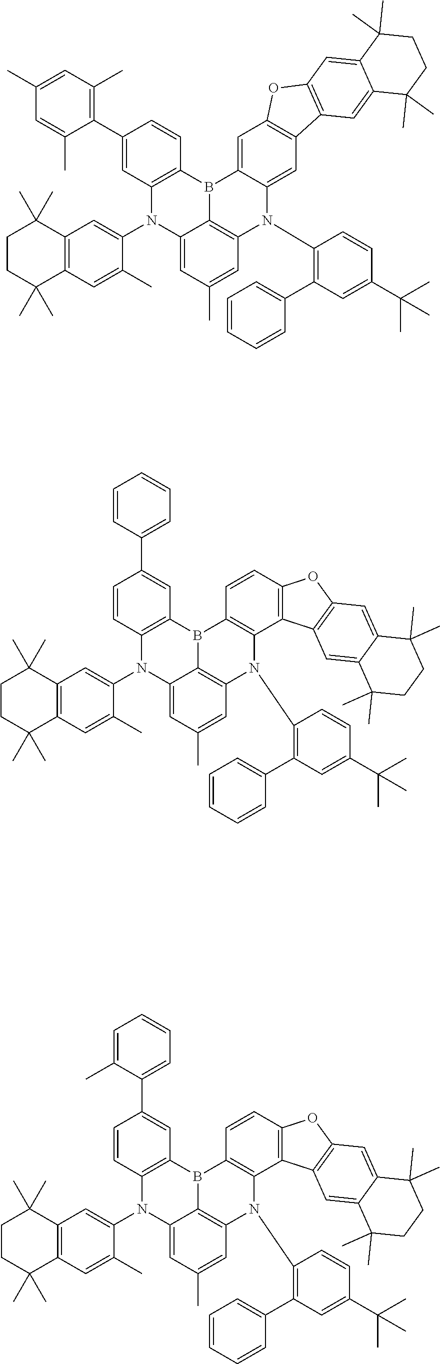

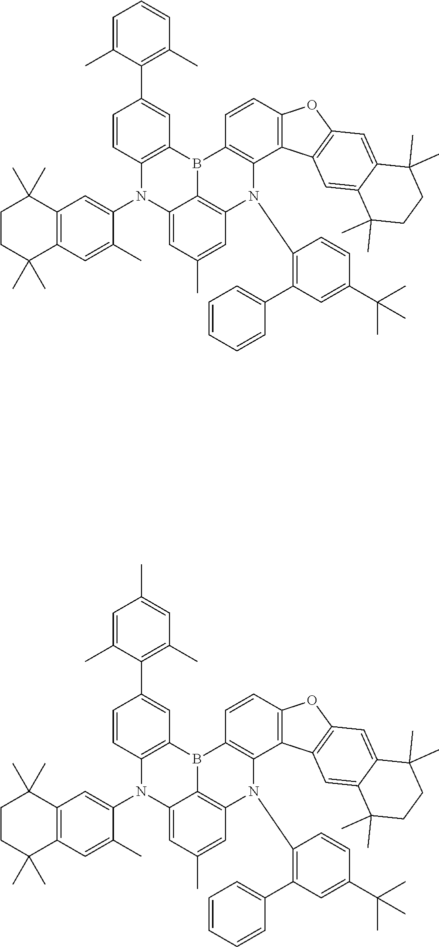 [SMILES: Cc1cc2c3c(c1)N(c1ccc(C(C)(C)C)cc1-c1ccccc1)c1c(ccc4oc5cc6c(cc5c14)C(C)(C)CCC6(C)C)B3c1cc(-c3c(C)cccc3C)ccc1N2c1cc2c(cc1C)C(C)(C)CCC2(C)C ; Cc1cc(C)c(-c2ccc3c(c2)B2c4ccc5oc6cc7c(cc6c5c4N(c4ccc(C(C)(C)C)cc4-c4ccccc4)c4cc(C)cc(c42)N3c2cc3c(cc2C)C(C)(C)CCC3(C)C)C(C)(C)CCC7(C)C)c(C)c1]

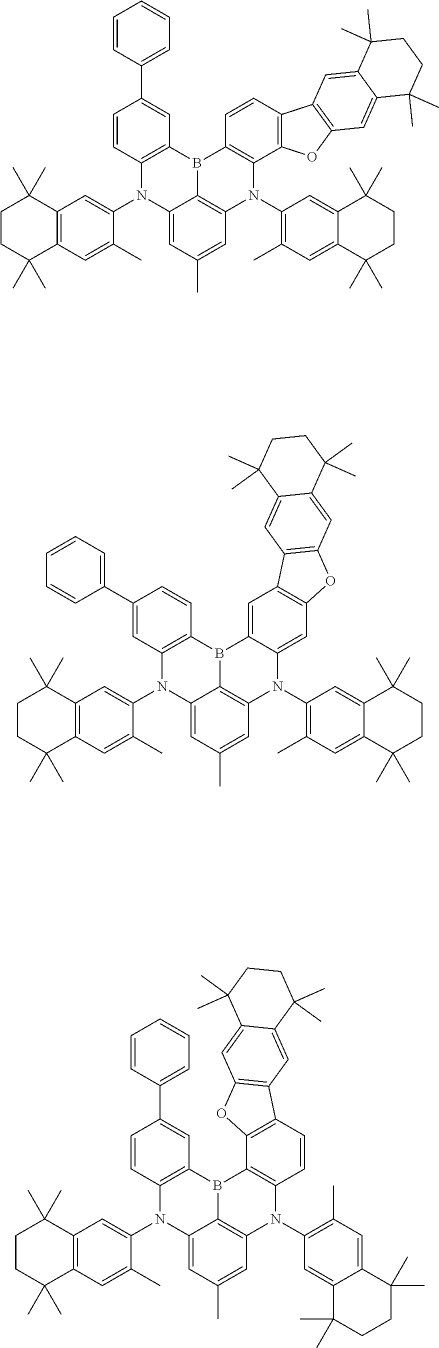 [SMILES: Cc1cc2c3c(c1)N(c1cc4c(cc1C)C(C)(C)CCC4(C)C)c1c(ccc4c1oc1cc5c(cc14)C(C)(C)CCC5(C)C)B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4oc5cc6c(cc5c4cc1B3c1ccc(-c3ccccc3)cc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(oc5cc6c(cc54)C(C)(C)CCC6(C)C)c1B3c1cc(-c3ccccc3)ccc1N2c1cc2c(cc1C)C(C)(C)CCC2(C)C]

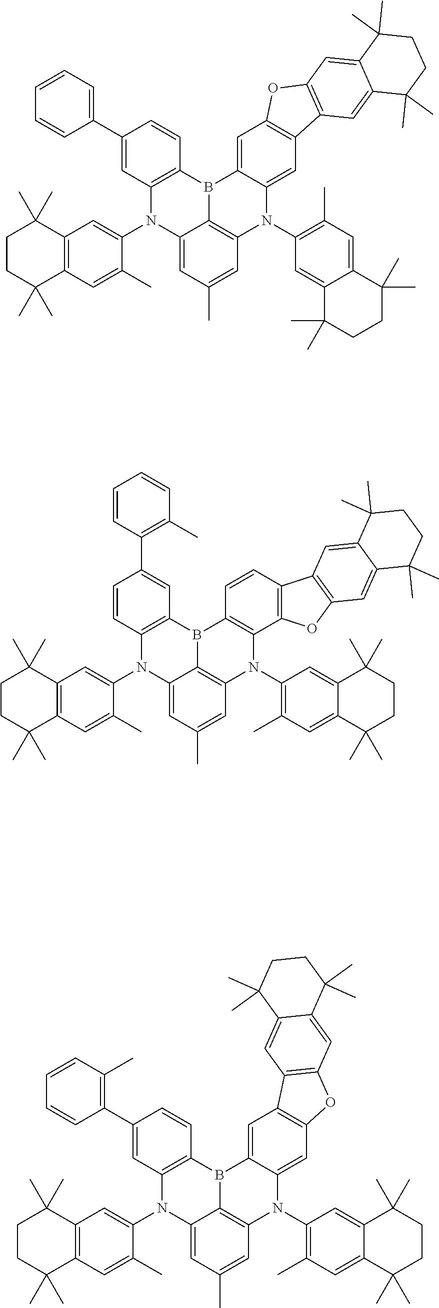 [SMILES: Cc1cc2c3c(c1)N(c1cc4c(cc1C)C(C)(C)CCC4(C)C)c1cc4c(cc1B3c1ccc(-c3ccccc3)cc1N2c1cc2c(cc1C)C(C)(C)CCC2(C)C)oc1cc2c(cc14)C(C)(C)CCC2(C)C ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4oc5cc6c(cc5c4cc1B3c1ccc(-c3ccccc3C)cc1N2c1cc2c(cc1C)C(C)(C)CCC2(C)C)C(C)(C)CCC6(C)C]

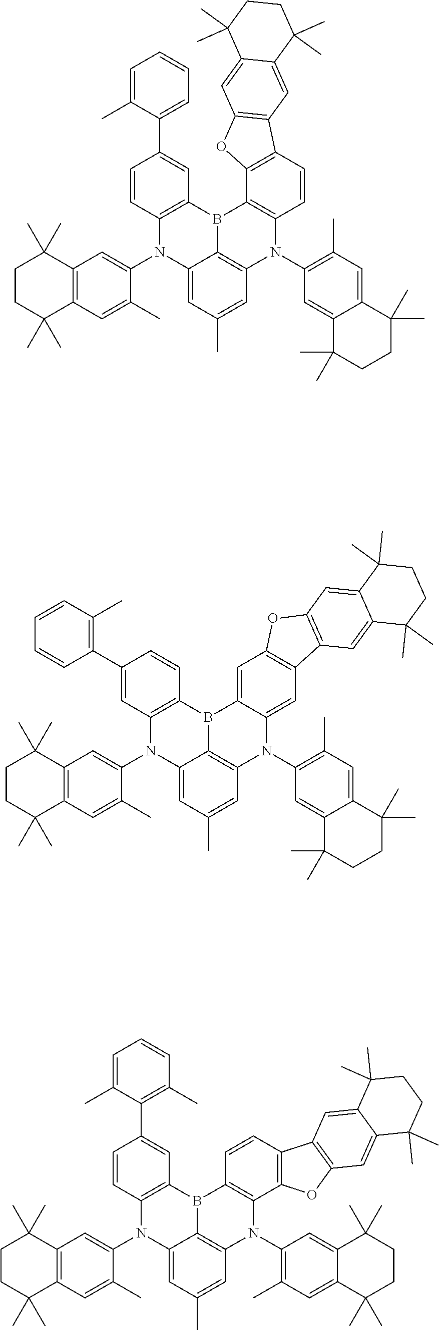 [SMILES: Cc1cc2c3c(c1)N(c1cc4c(cc1C)C(C)(C)CCC4(C)C)c1ccc4c(oc5cc6c(cc54)C(C)(C)CCC6(C)C)c1B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3ccccc3C)cc1N2c1cc2c(cc1C)C(C)(C)CCC2(C)C)oc1cc2c(cc14)C(C)(C)CCC2(C)C ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc(-c3c(C)cccc3C)ccc1N2c1cc2c(cc1C)C(C)(C)CCC2(C)C]

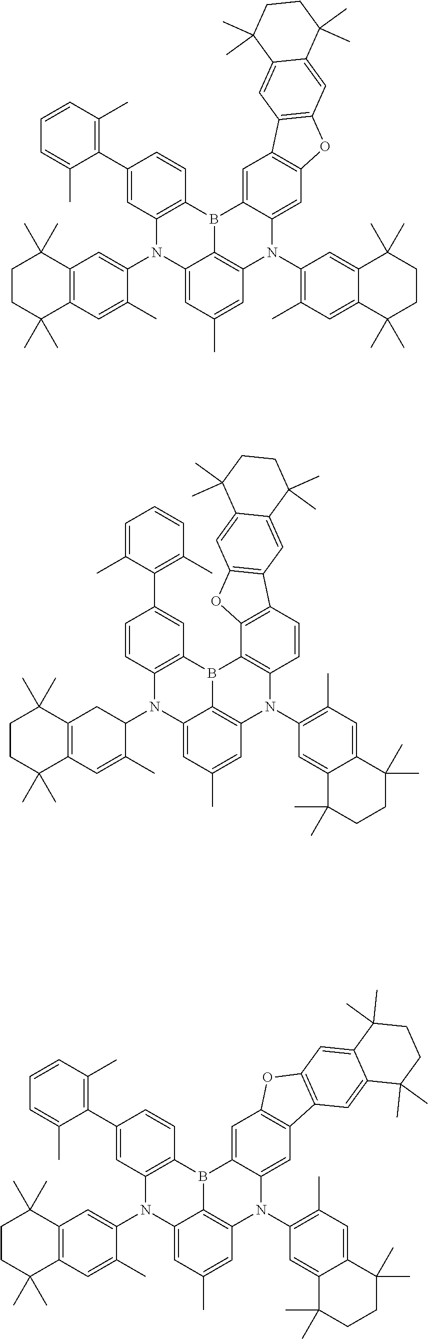 [SMILES: Cc1cc2c3c(c1)N(c1cc4c(cc1C)C(C)(C)CCC4(C)C)c1cc4oc5cc6c(cc5c4cc1B3c1ccc(-c3c(C)cccc3C)cc1N2c1cc2c(cc1C)C(C)(C)CCC2(C)C)C(C)(C)CCC6(C)C ; CC1=CC2=C(CC1N1c3ccc(-c4c(C)cccc4C)cc3B3c4c(cc(C)cc41)N(c1cc4c(cc1C)C(C)(C)CCC4(C)C)c1ccc4c(oc5cc6c(cc54)C(C)(C)CCC6(C)C)c13)C(C)(C)CCC2(C)C ; Cc1cc2c3c(c1)N(c1cc4c(cc1C)C(C)(C)CCC4(C)C)c1cc4c(cc1B3c1ccc(-c3c(C)cccc3C)cc1N2c1cc2c(cc1C)C(C)(C)CCC2(C)C)oc1cc2c(cc14)C(C)(C)CCC2(C)C]

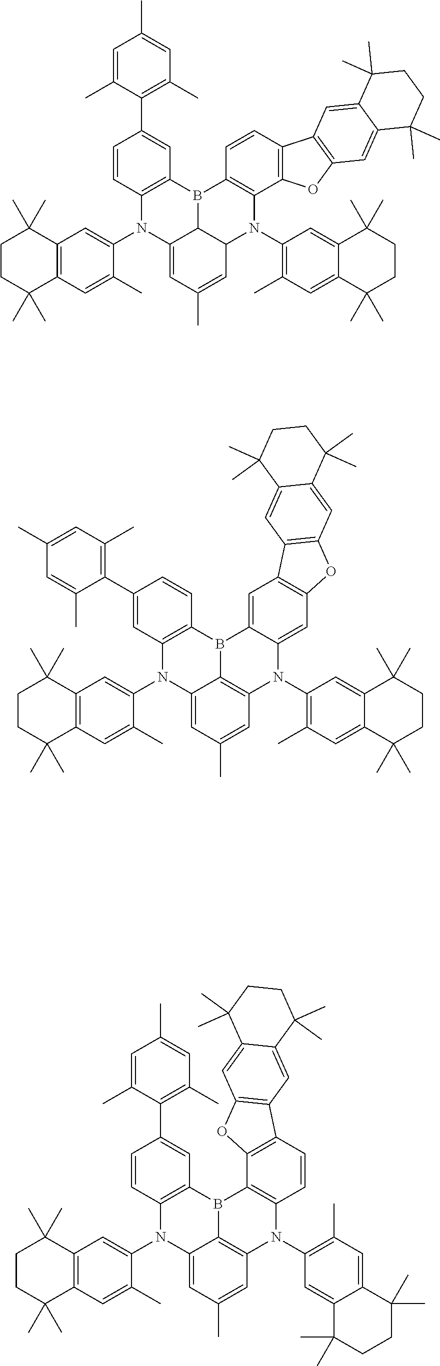

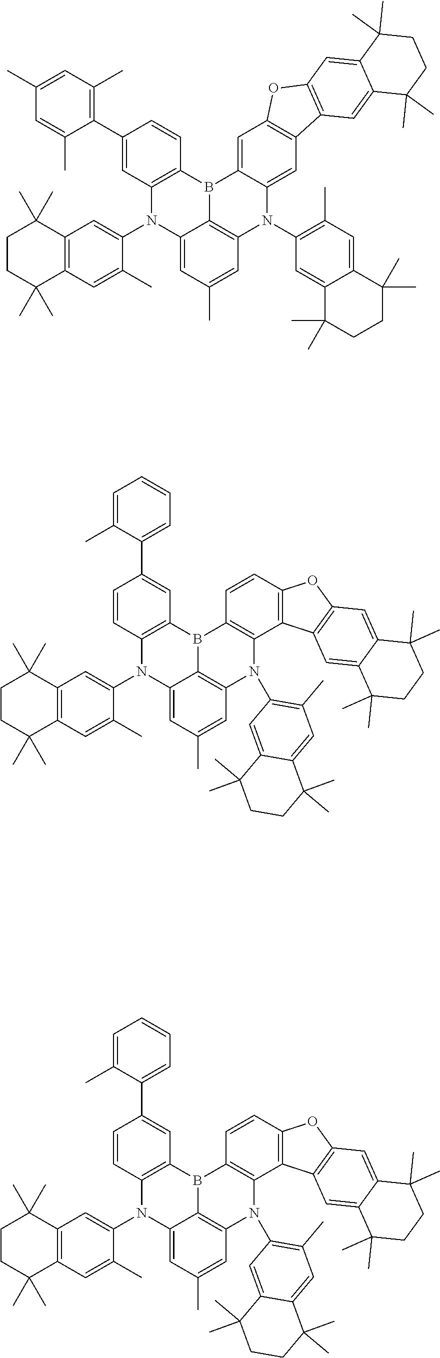

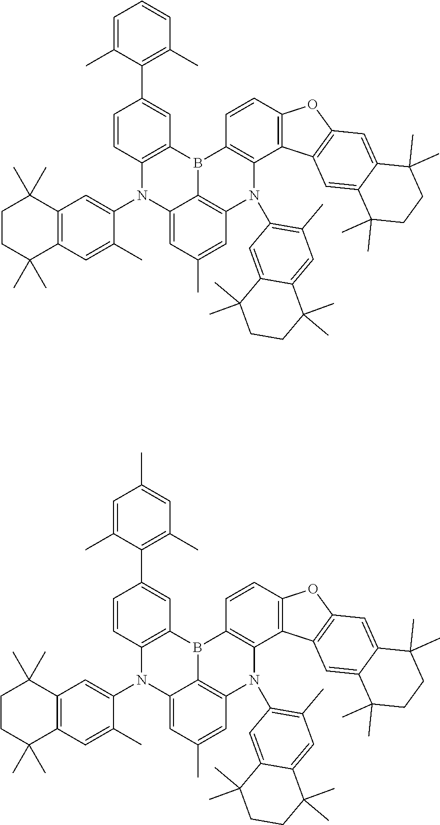 [SMILES: Cc1cc2c3c(c1)N(c1cc4c(cc1C)C(C)(C)CCC4(C)C)c1c(ccc4oc5cc6c(cc5c14)C(C)(C)CCC6(C)C)B3c1cc(-c3c(C)cccc3C)ccc1N2c1cc2c(cc1C)C(C)(C)CCC2(C)C ; Cc1cc(C)c(-c2ccc3c(c2)B2c4ccc5oc6cc7c(cc6c5c4N(c4cc5c(cc4C)C(C)(C)CCC5(C)C)c4cc(C)cc(c42)N3c2cc3c(cc2C)C(C)(C)CCC3(C)C)C(C)(C)CCC7(C)C)c(C)c1]

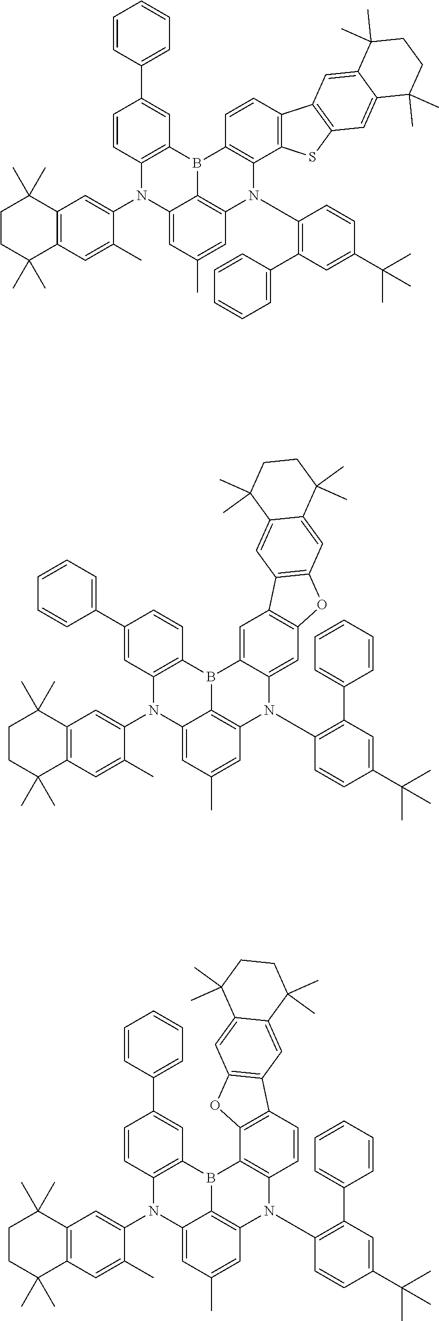 [SMILES: Cc1cc2c3c(c1)N(c1ccc(C(C)(C)C)cc1-c1ccccc1)c1c(ccc4c1sc1cc5c(cc14)C(C)(C)CCC5(C)C)B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1cc4oc5cc6c(cc5c4cc1B3c1ccc(-c3ccccc3)cc1N2c1cc2c(cc1C)C(C)(C)CCC2(C)C)C(C)(C)CCC6(C)C ; Cc1cc2c3c(c1)N(c1ccc(C(C)(C)C)cc1-c1ccccc1)c1ccc4c(oc5cc6c(cc54)C(C)(C)CCC6(C)C)c1B3c1cc(-c3ccccc3)ccc1N2c1cc2c(cc1C)C(C)(C)CCC2(C)C]

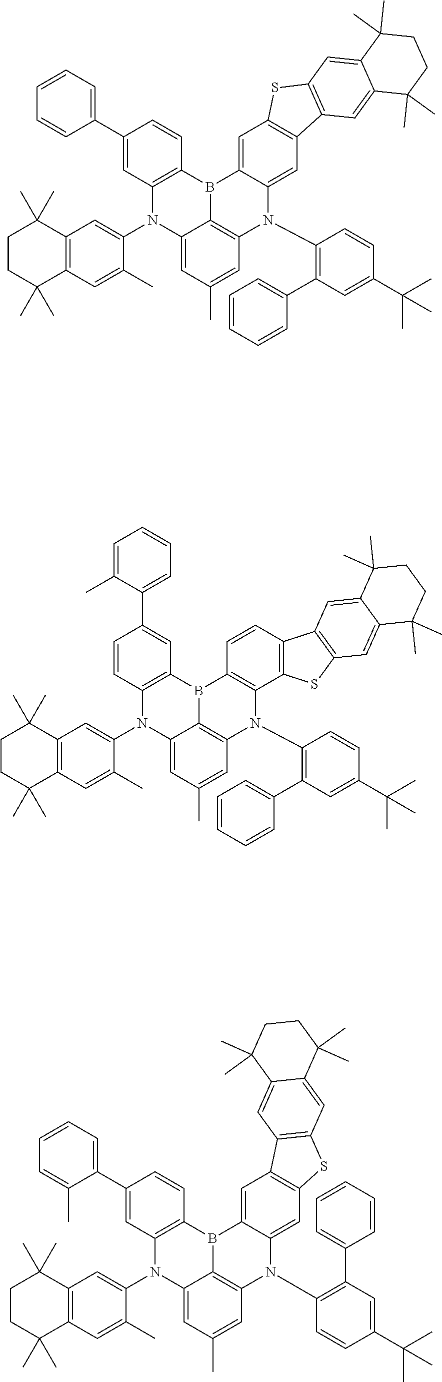 [SMILES: Cc1cc2c3c(c1)N(c1ccc(C(C)(C)C)cc1-c1ccccc1)c1cc4c(cc1B3c1ccc(-c3ccccc3)cc1N2c1cc2c(cc1C)C(C)(C)CCC2(C)C)sc1cc2c(cc14)C(C)(C)CCC2(C)C ; Cc1cc2c3c(c1)N(c1ccc(C(C)(C)C)cc1-c1ccccc1)c1c(ccc4c1sc1cc5c(cc14)C(C)(C)CCC5(C)C)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4sc5cc6c(cc5c4cc1B3c1ccc(-c3ccccc3C)cc1N2c1cc2c(cc1C)C(C)(C)CCC2(C)C)C(C)(C)CCC6(C)C]

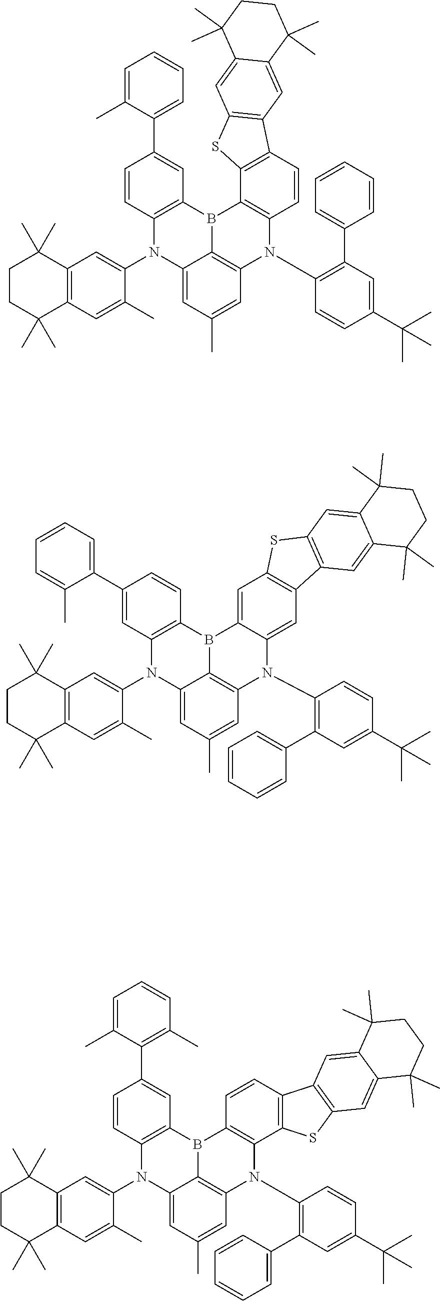 [SMILES: Cc1cc2c3c(c1)N(c1ccc(C(C)(C)C)cc1-c1ccccc1)c1ccc4c(sc5cc6c(cc54)C(C)(C)CCC6(C)C)c1B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3ccccc3C)cc1N2c1cc2c(cc1C)C(C)(C)CCC2(C)C)sc1cc2c(cc14)C(C)(C)CCC2(C)C ; Cc1cc2c3c(c1)N(c1ccc(C(C)(C)C)cc1-c1ccccc1)c1c(ccc4c1sc1cc5c(cc14)C(C)(C)CCC5(C)C)B3c1cc(-c3c(C)cccc3C)ccc1N2c1cc2c(cc1C)C(C)(C)CCC2(C)C]

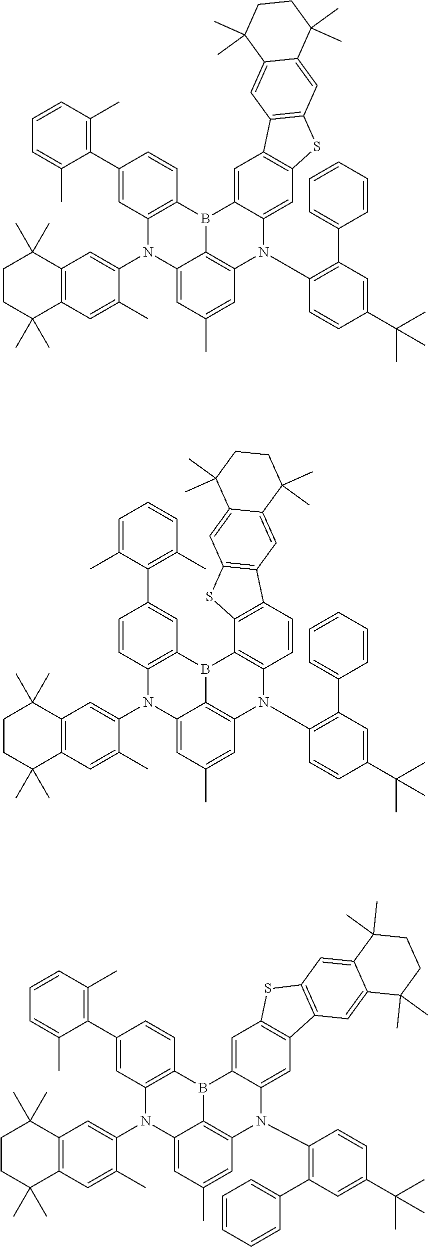 [SMILES: Cc1cc2c3c(c1)N(c1ccc(C(C)(C)C)cc1-c1ccccc1)c1cc4sc5cc6c(cc5c4cc1B3c1ccc(-c3c(C)cccc3C)cc1N2c1cc2c(cc1C)C(C)(C)CCC2(C)C)C(C)(C)CCC6(C)C ; Cc1cc2c3c(c1)N(c1ccc(C(C)(C)C)cc1-c1ccccc1)c1ccc4c(sc5cc6c(cc54)C(C)(C)CCC6(C)C)c1B3c1cc(-c3c(C)cccc3C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3c(C)cccc3C)cc1N2c1cc2c(cc1C)C(C)(C)CCC2(C)C)sc1cc2c(cc14)C(C)(C)CCC2(C)C]

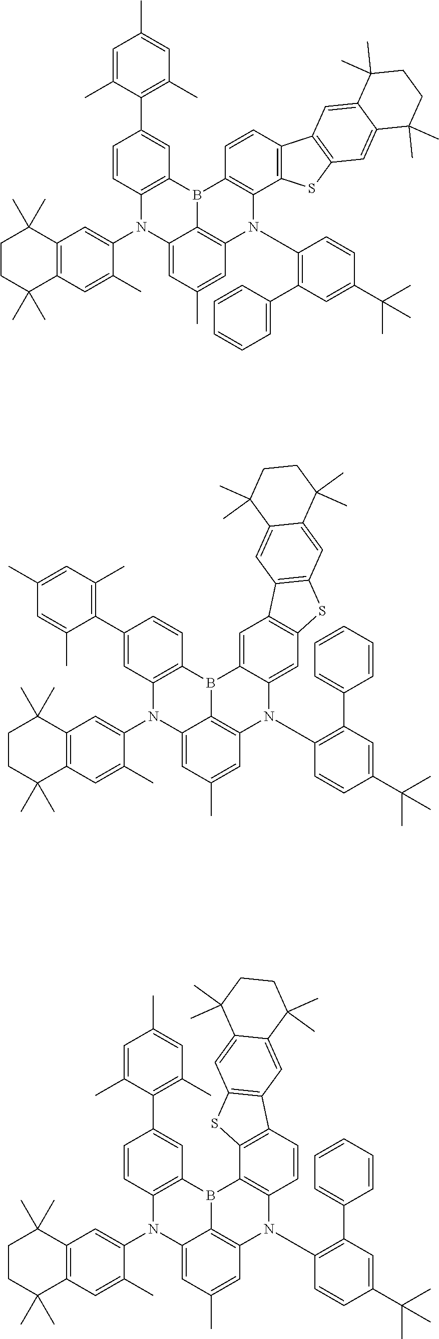

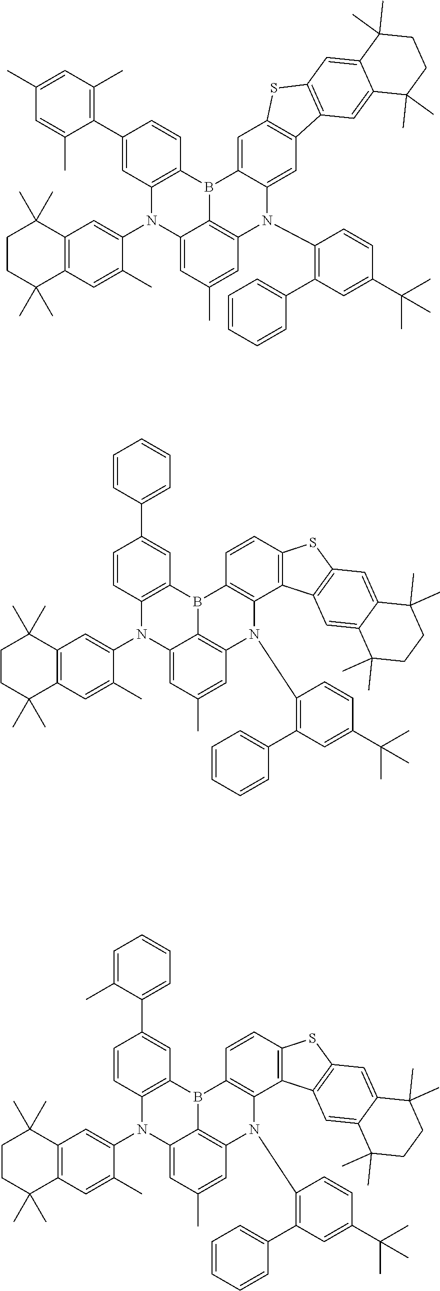

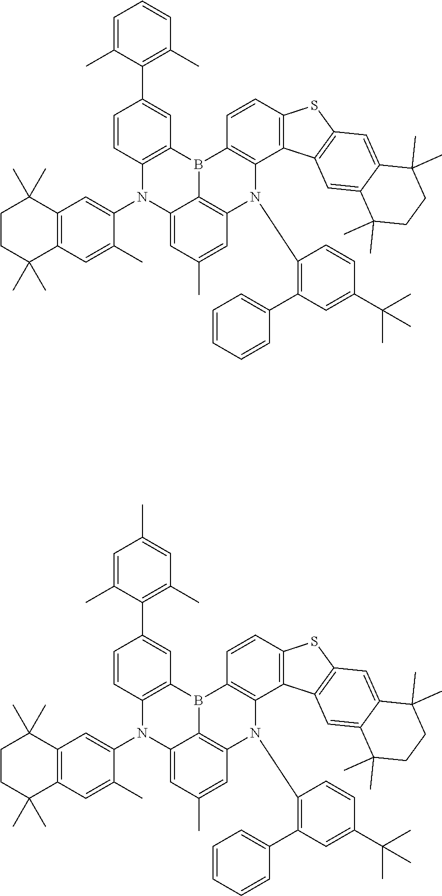 [SMILES: Cc1cc2c3c(c1)N(c1ccc(C(C)(C)C)cc1-c1ccccc1)c1c(ccc4sc5cc6c(cc5c14)C(C)(C)CCC6(C)C)B3c1cc(-c3c(C)cccc3C)ccc1N2c1cc2c(cc1C)C(C)(C)CCC2(C)C ; Cc1cc(C)c(-c2ccc3c(c2)B2c4ccc5sc6cc7c(cc6c5c4N(c4ccc(C(C)(C)C)cc4-c4ccccc4)c4cc(C)cc(c42)N3c2cc3c(cc2C)C(C)(C)CCC3(C)C)C(C)(C)CCC7(C)C)c(C)c1]

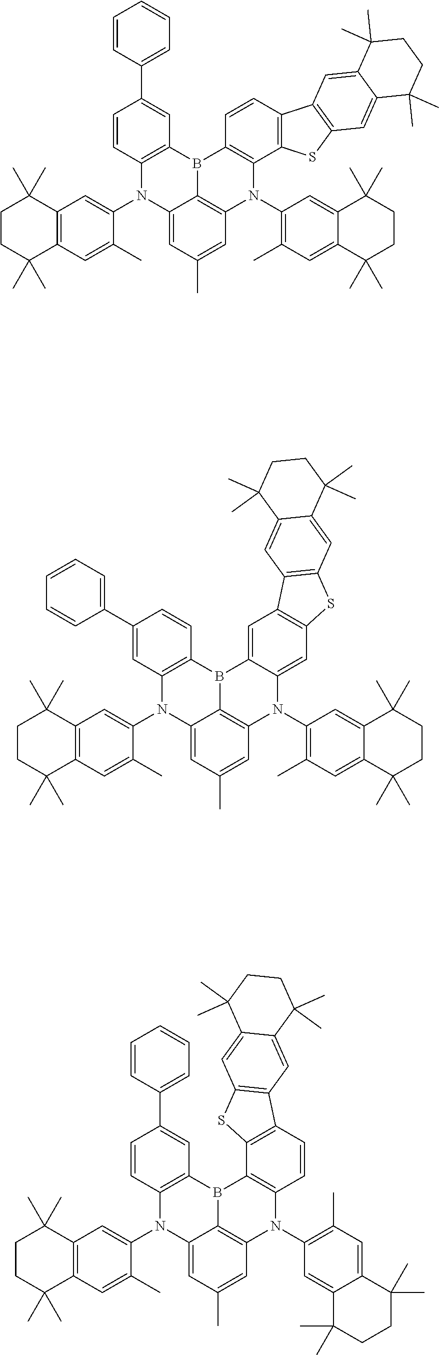 [SMILES: Cc1cc2c3c(c1)N(c1cc4c(cc1C)C(C)(C)CCC4(C)C)c1c(ccc4c1sc1cc5c(cc14)C(C)(C)CCC5(C)C)B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4sc5cc6c(cc5c4cc1B3c1ccc(-c3ccccc3)cc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(sc5cc6c(cc54)C(C)(C)CCC6(C)C)c1B3c1cc(-c3ccccc3)ccc1N2c1cc2c(cc1C)C(C)(C)CCC2(C)C]

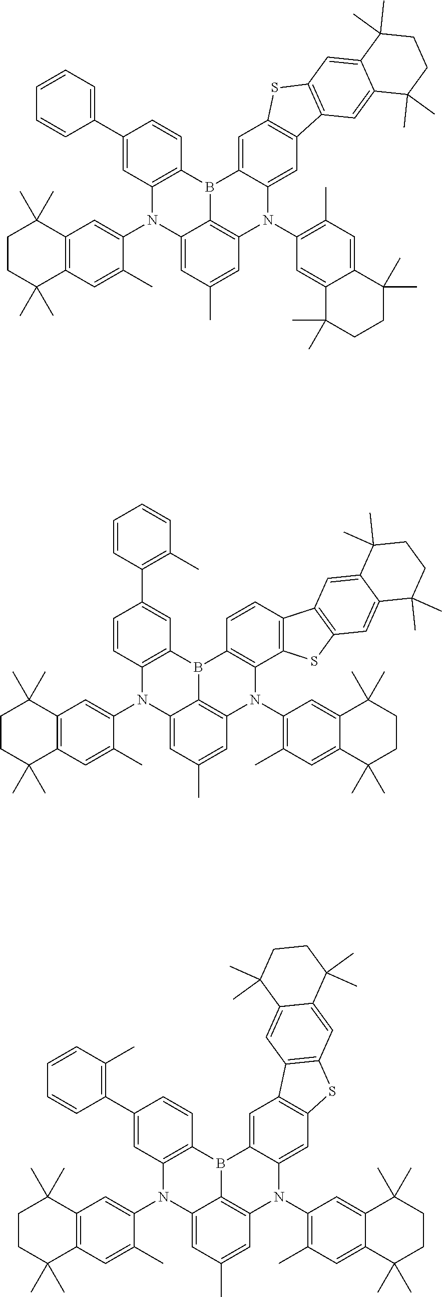 [SMILES: Cc1cc2c3c(c1)N(c1cc4c(cc1C)C(C)(C)CCC4(C)C)c1cc4c(cc1B3c1ccc(-c3ccccc3)cc1N2c1cc2c(cc1C)C(C)(C)CCC2(C)C)sc1cc2c(cc14)C(C)(C)CCC2(C)C ; Cc1cc2c3c(c1)N(c1cc4c(cc1C)C(C)(C)CCC4(C)C)c1c(ccc4c1sc1cc5c(cc14)C(C)(C)CCC5(C)C)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4sc5cc6c(cc5c4cc1B3c1ccc(-c3ccccc3C)cc1N2c1cc2c(cc1C)C(C)(C)CCC2(C)C)C(C)(C)CCC6(C)C]

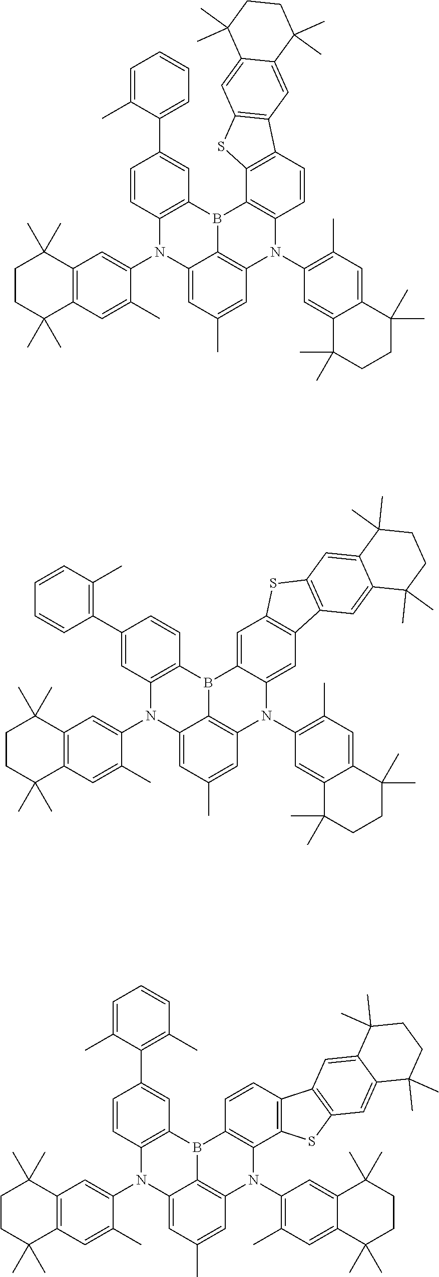 [SMILES: Cc1cc2c3c(c1)N(c1cc4c(cc1C)C(C)(C)CCC4(C)C)c1ccc4c(sc5cc6c(cc54)C(C)(C)CCC6(C)C)c1B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3ccccc3C)cc1N2c1cc2c(cc1C)C(C)(C)CCC2(C)C)sc1cc2c(cc14)C(C)(C)CCC2(C)C ; Cc1cc2c3c(c1)N(c1cc4c(cc1C)C(C)(C)CCC4(C)C)c1c(ccc4c1sc1cc5c(cc14)C(C)(C)CCC5(C)C)B3c1cc(-c3c(C)cccc3C)ccc1N2c1cc2c(cc1C)C(C)(C)CCC2(C)C]

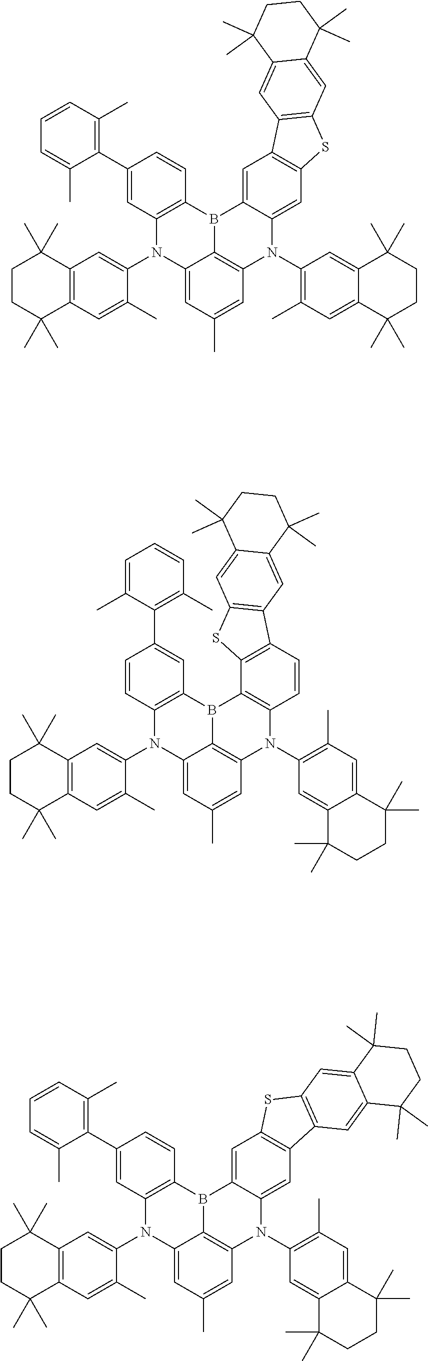 [SMILES: Cc1cc2c3c(c1)N(c1cc4c(cc1C)C(C)(C)CCC4(C)C)c1cc4sc5cc6c(cc5c4cc1B3c1ccc(-c3c(C)cccc3C)cc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(sc5cc6c(cc54)C(C)(C)CCC6(C)C)c1B3c1cc(-c3c(C)cccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3c(C)cccc3C)cc1N2c1cc2c(cc1C)C(C)(C)CCC2(C)C)sc1cc2c(cc14)C(C)(C)CCC2(C)C]

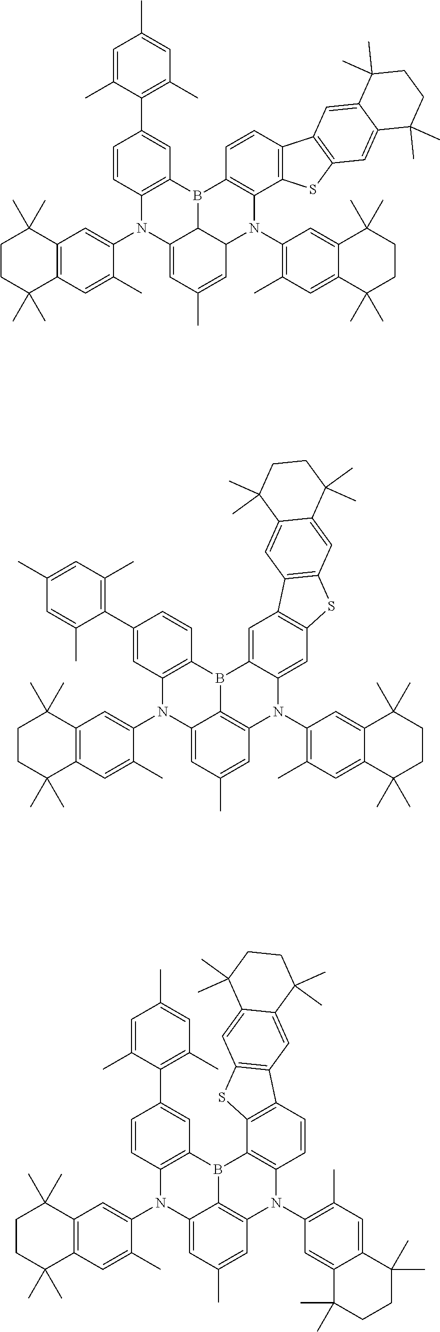

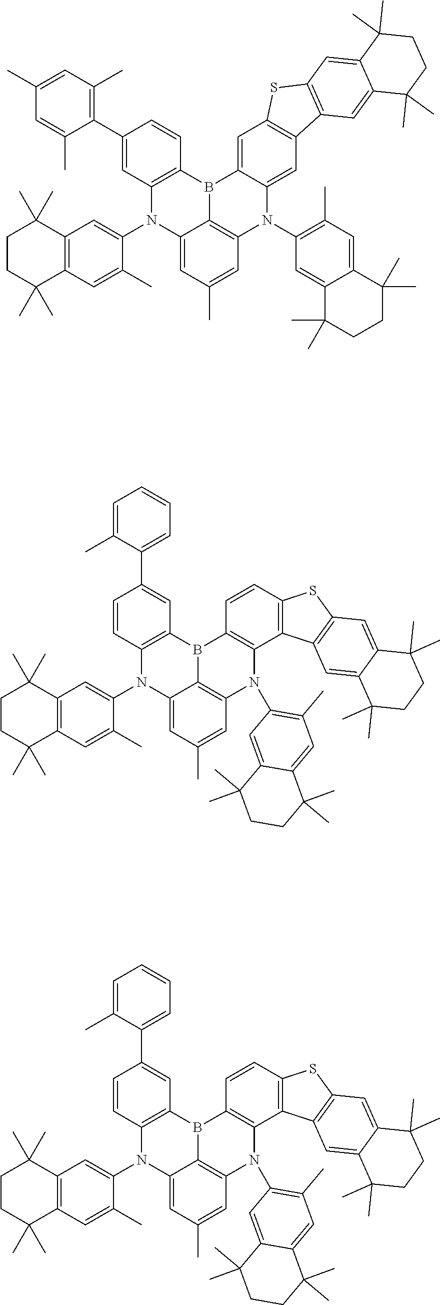

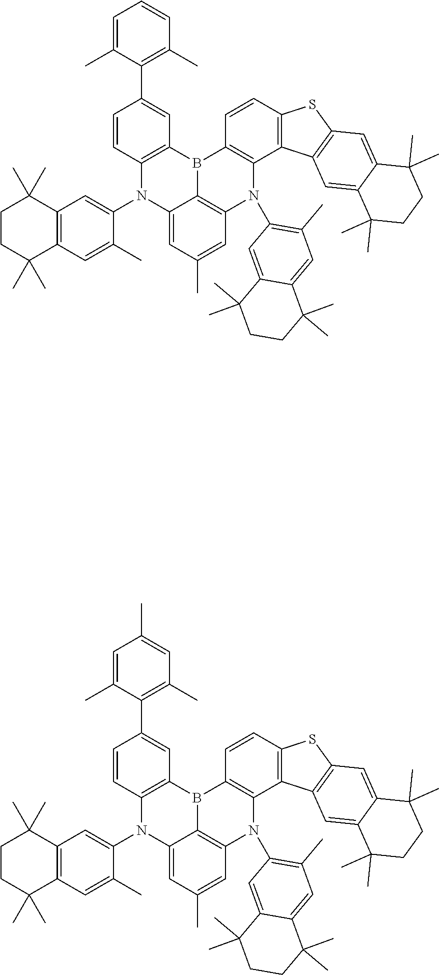 [SMILES: Cc1cc2c3c(c1)N(c1cc4c(cc1C)C(C)(C)CCC4(C)C)c1c(ccc4sc5cc6c(cc5c14)C(C)(C)CCC6(C)C)B3c1cc(-c3c(C)cccc3C)ccc1N2c1cc2c(cc1C)C(C)(C)CCC2(C)C ; Cc1cc(C)c(-c2ccc3c(c2)B2c4ccc5sc6cc7c(cc6c5c4N(c4cc5c(cc4C)C(C)(C)CCC5(C)C)c4cc(C)cc(c42)N3c2cc3c(cc2C)C(C)(C)CCC3(C)C)C(C)(C)CCC7(C)C)c(C)c1]

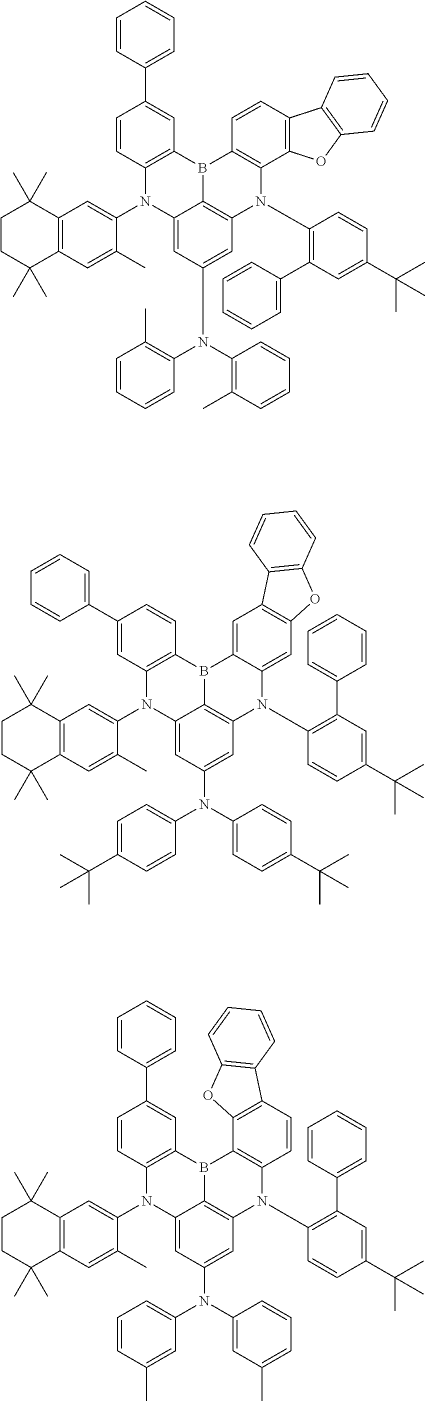 [SMILES: Cc1ccccc1N(c1cc2c3c(c1)N(c1ccc(C(C)(C)C)cc1-c1ccccc1)c1c(ccc4c1oc1ccccc14)B3c1cc(-c3ccccc3)ccc1N2c1cc2c(cc1C)C(C)(C)CCC2(C)C)c1ccccc1C ; Cc1cc2c(cc1N1c3cc(-c4ccccc4)ccc3B3c4cc5c(cc4N(c4ccc(C(C)(C)C)cc4-c4ccccc4)c4cc(N(c6ccc(C(C)(C)C)cc6)c6ccc(C(C)(C)C)cc6)cc1c43)oc1ccccc15)C(C)(C)CCC2(C)C ; Cc1cccc(N(c2cccc(C)c2)c2cc3c4c(c2)N(c2ccc(C(C)(C)C)cc2-c2ccccc2)c2ccc5c(oc6ccccc65)c2B4c2cc(-c4ccccc4)ccc2N3c2cc3c(cc2C)C(C)(C)CCC3(C)C)c1]

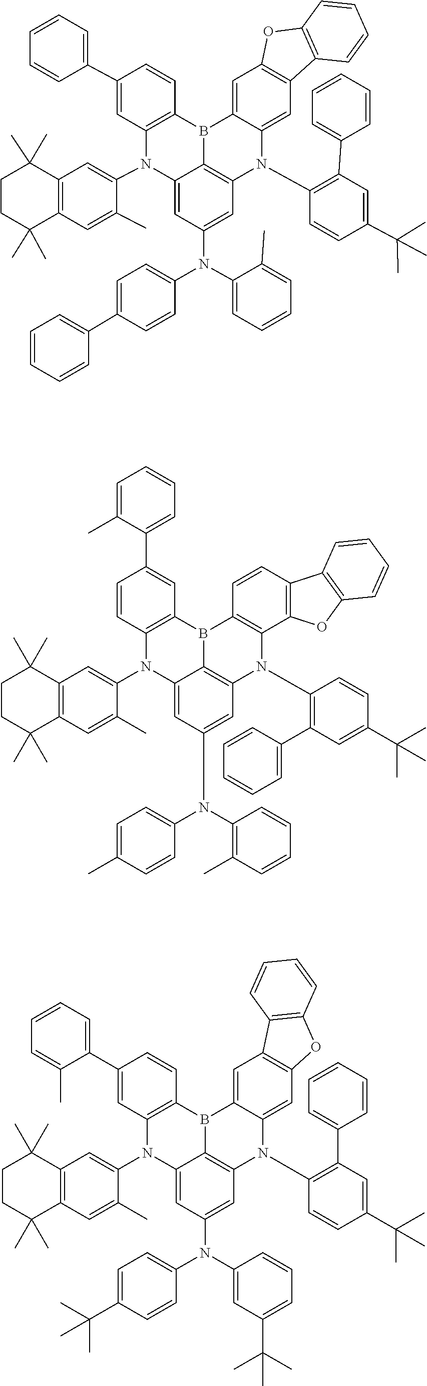 [SMILES: Cc1ccccc1N(c1ccc(-c2ccccc2)cc1)c1cc2c3c(c1)N(c1ccc(C(C)(C)C)cc1-c1ccccc1)c1cc4c(cc1B3c1ccc(-c3ccccc3)cc1N2c1cc2c(cc1C)C(C)(C)CCC2(C)C)oc1ccccc14 ; Cc1ccc(N(c2cc3c4c(c2)N(c2ccc(C(C)(C)C)cc2-c2ccccc2)c2c(ccc5c2oc2ccccc25)B4c2cc(-c4ccccc4C)ccc2N3c2cc3c(cc2C)C(C)(C)CCC3(C)C)c2ccccc2C)cc1 ; Cc1ccccc1-c1ccc2c(c1)N(c1cc3c(cc1C)C(C)(C)CCC3(C)C)c1cc(N(c3ccc(C(C)(C)C)cc3)c3cccc(C(C)(C)C)c3)cc3c1B2c1cc2c(cc1N3c1ccc(C(C)(C)C)cc1-c1ccccc1)oc1ccccc12]

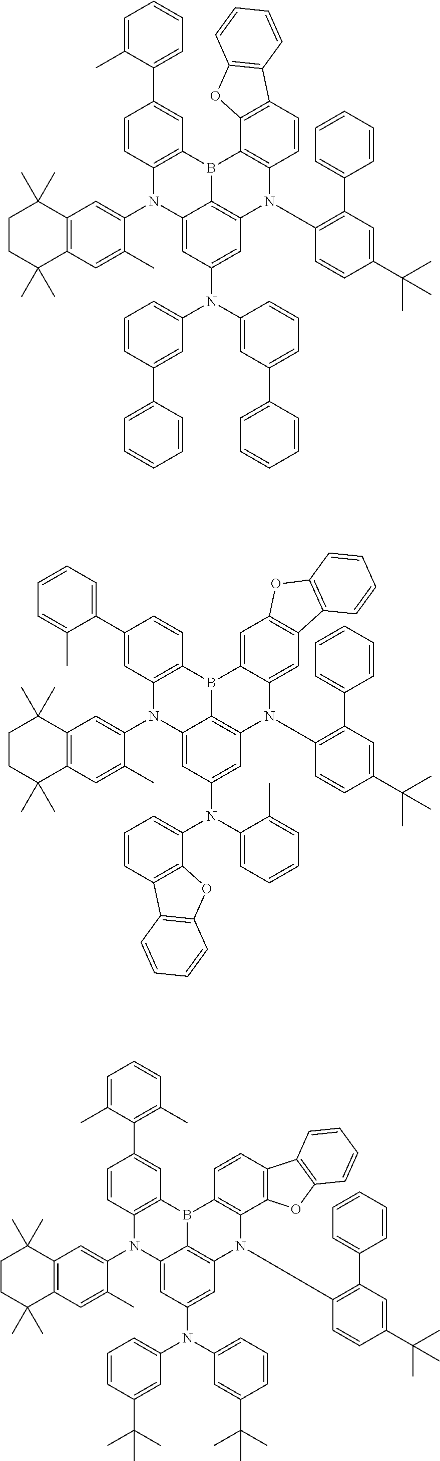

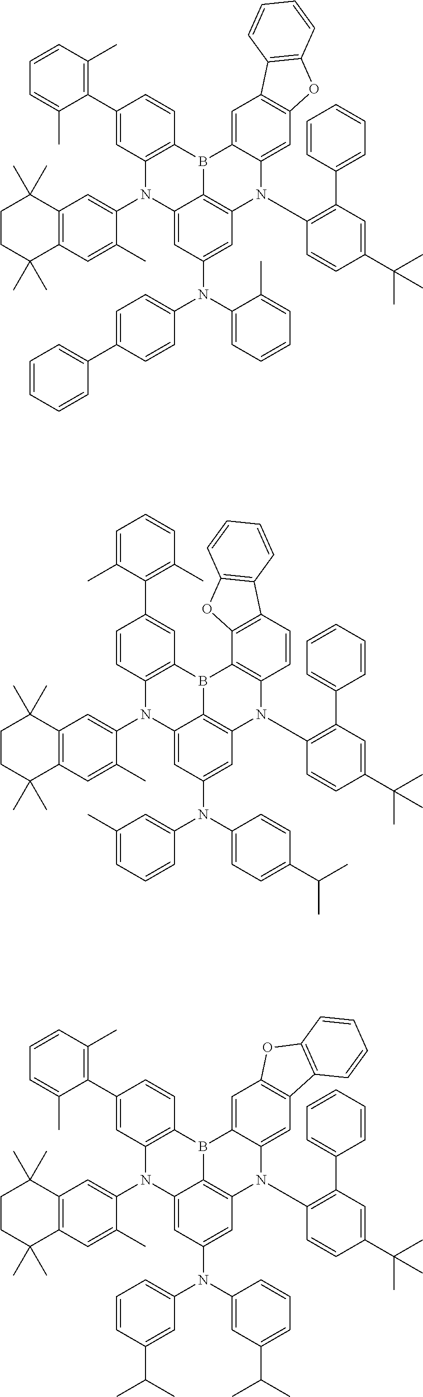 [SMILES: Cc1ccccc1N(c1ccc(-c2ccccc2)cc1)c1cc2c3c(c1)N(c1ccc(C(C)(C)C)cc1-c1ccccc1)c1cc4oc5ccccc5c4cc1B3c1ccc(-c3c(C)cccc3C)cc1N2c1cc2c(cc1C)C(C)(C)CCC2(C)C ; Cc1cccc(N(c2ccc(C(C)C)cc2)c2cc3c4c(c2)N(c2ccc(C(C)(C)C)cc2-c2ccccc2)c2ccc5c(oc6ccccc65)c2B4c2cc(-c4c(C)cccc4C)ccc2N3c2cc3c(cc2C)C(C)(C)CCC3(C)C)c1 ; Cc1cc2c(cc1N1c3cc(-c4c(C)cccc4C)ccc3B3c4cc5oc6ccccc6c5cc4N(c4ccc(C(C)(C)C)cc4-c4ccccc4)c4cc(N(c5cccc(C(C)C)c5)c5cccc(C(C)C)c5)cc1c43)C(C)(C)CCC2(C)C]

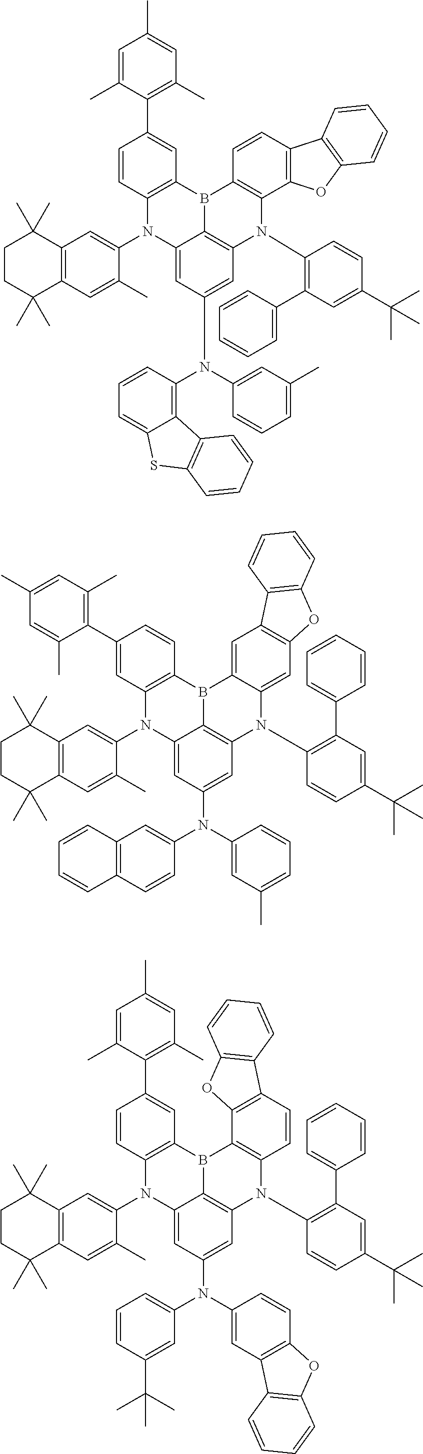

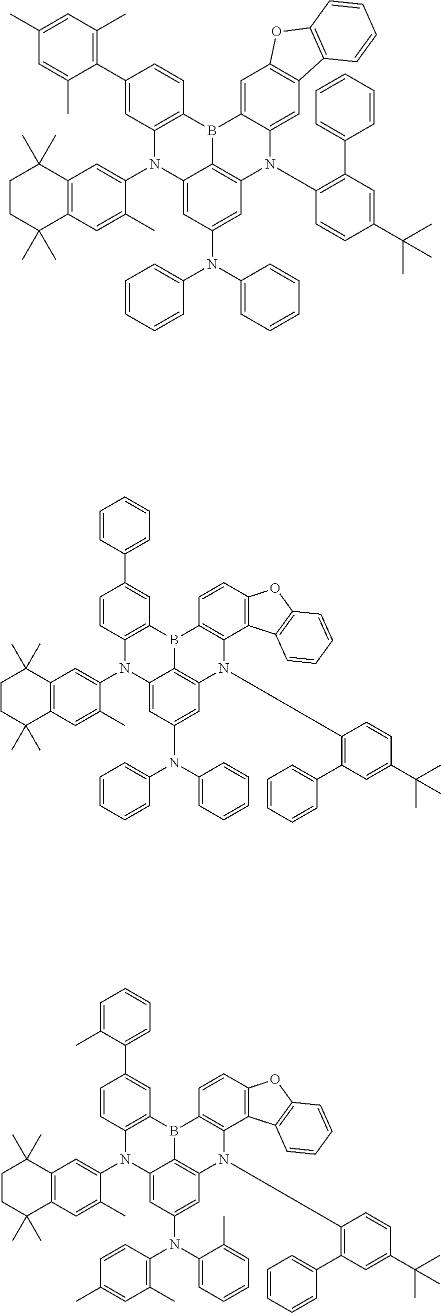 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3oc5ccccc5c3cc2N4c2ccc(C(C)(C)C)cc2-c2ccccc2)c(C)c1 ; Cc1cc2c(cc1N1c3ccc(-c4ccccc4)cc3B3c4ccc5oc6ccccc6c5c4N(c4ccc(C(C)(C)C)cc4-c4ccccc4)c4cc(N(c5ccccc5)c5ccccc5)cc1c43)C(C)(C)CCC2(C)C ; Cc1ccc(N(c2cc3c4c(c2)N(c2ccc(C(C)(C)C)cc2-c2ccccc2)c2c(ccc5oc6ccccc6c25)B4c2cc(-c4ccccc4C)ccc2N3c2cc3c(cc2C)C(C)(C)CCC3(C)C)c2ccccc2C)c(C)c1]

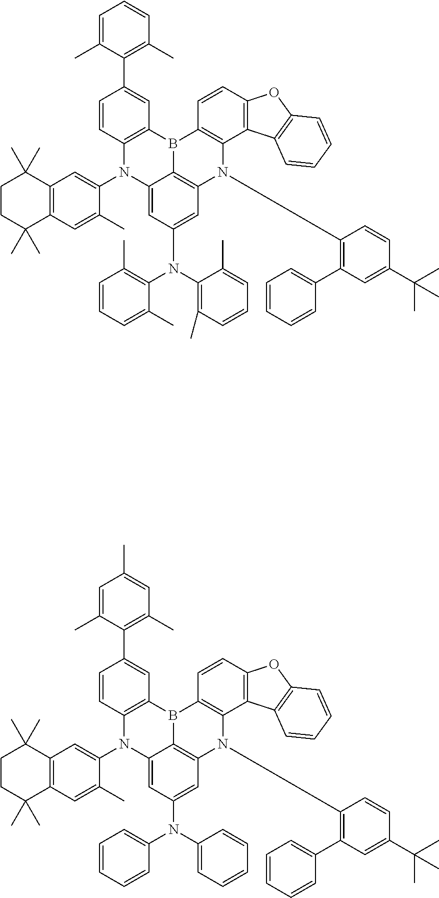 [SMILES: Cc1cc2c(cc1N1c3ccc(-c4c(C)cccc4C)cc3B3c4ccc5oc6ccccc6c5c4N(c4ccc(C(C)(C)C)cc4-c4ccccc4)c4cc(N(c5c(C)cccc5C)c5c(C)cccc5C)cc1c43)C(C)(C)CCC2(C)C ; Cc1cc(C)c(-c2ccc3c(c2)B2c4ccc5oc6ccccc6c5c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)c(C)c1]

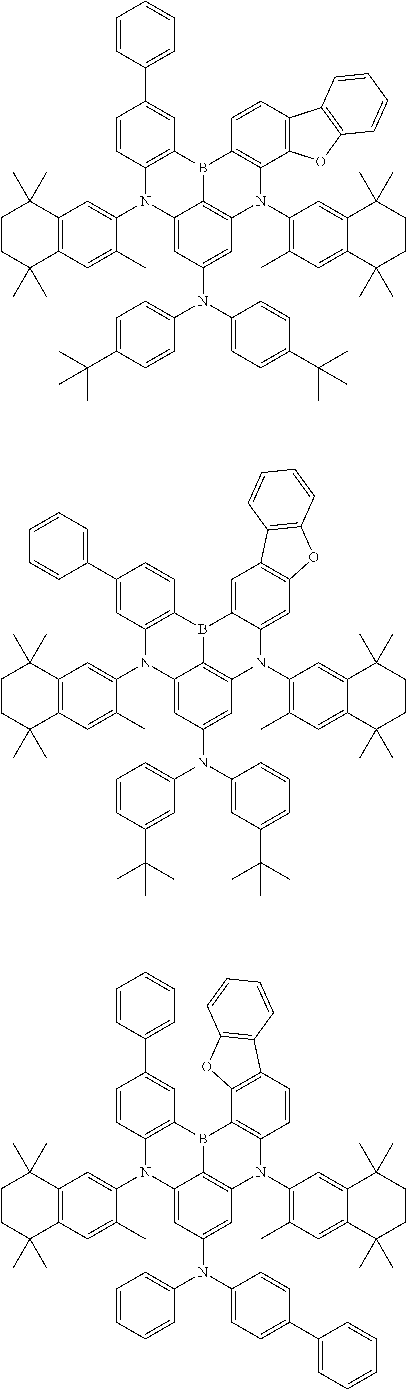 [SMILES: Cc1cc2c(cc1N1c3ccc(-c4ccccc4)cc3B3c4ccc5c(oc6ccccc65)c4N(c4cc5c(cc4C)C(C)(C)CCC5(C)C)c4cc(N(c5ccc(C(C)(C)C)cc5)c5ccc(C(C)(C)C)cc5)cc1c43)C(C)(C)CCC2(C)C ; Cc1cc2c(cc1N1c3cc(-c4ccccc4)ccc3B3c4cc5c(cc4N(c4cc6c(cc4C)C(C)(C)CCC6(C)C)c4cc(N(c6cccc(C(C)(C)C)c6)c6cccc(C(C)(C)C)c6)cc1c43)oc1ccccc15)C(C)(C)CCC2(C)C ; Cc1cc2c(cc1N1c3ccc(-c4ccccc4)cc3B3c4c1cc(N(c1ccccc1)c1ccc(-c5ccccc5)cc1)cc4N(c1cc4c(cc1C)C(C)(C)CCC4(C)C)c1ccc4c(oc5ccccc54)c13)C(C)(C)CCC2(C)C]

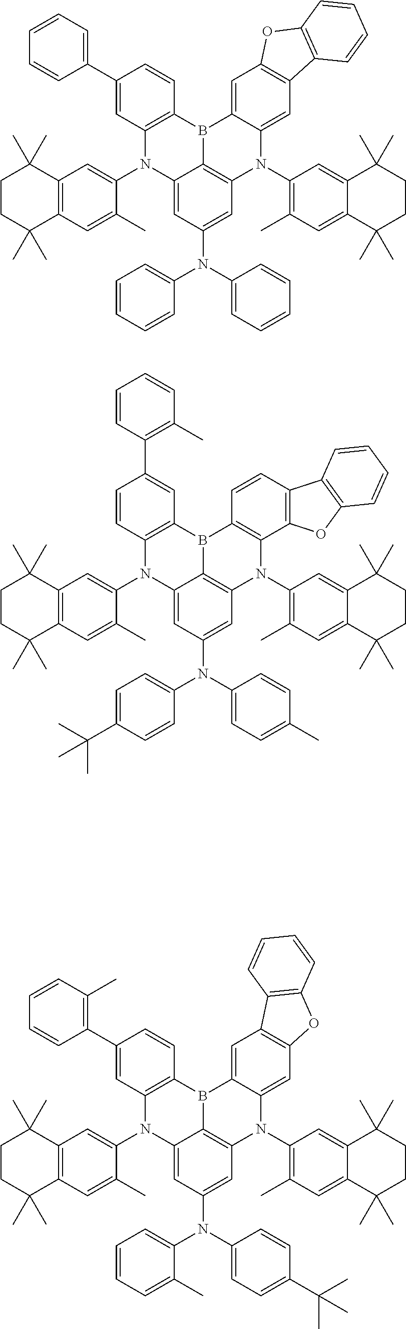

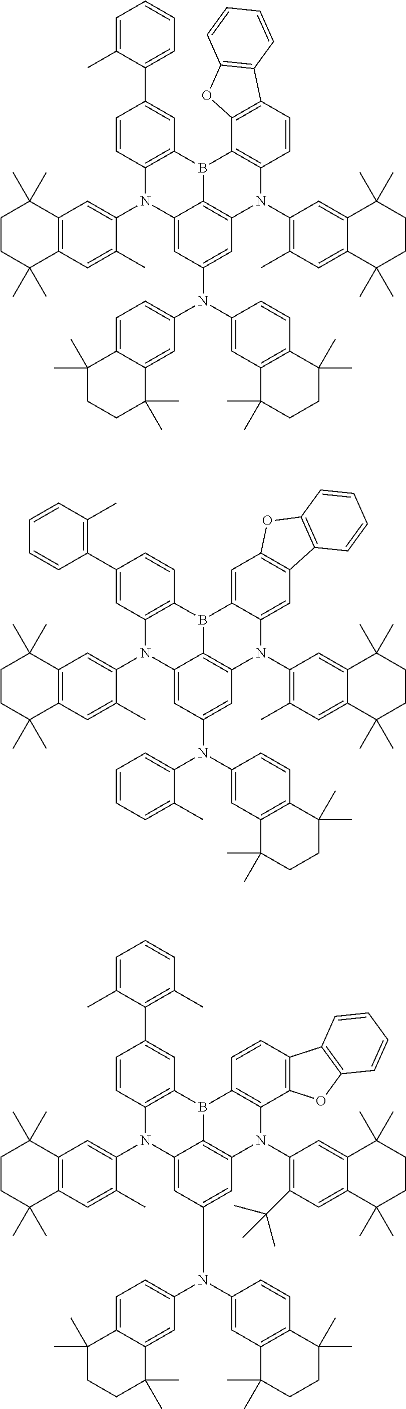

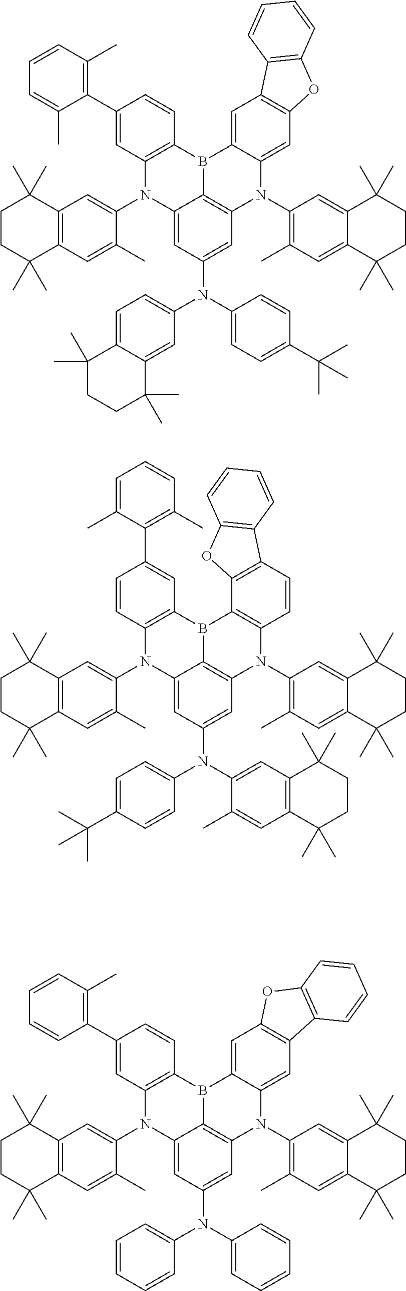

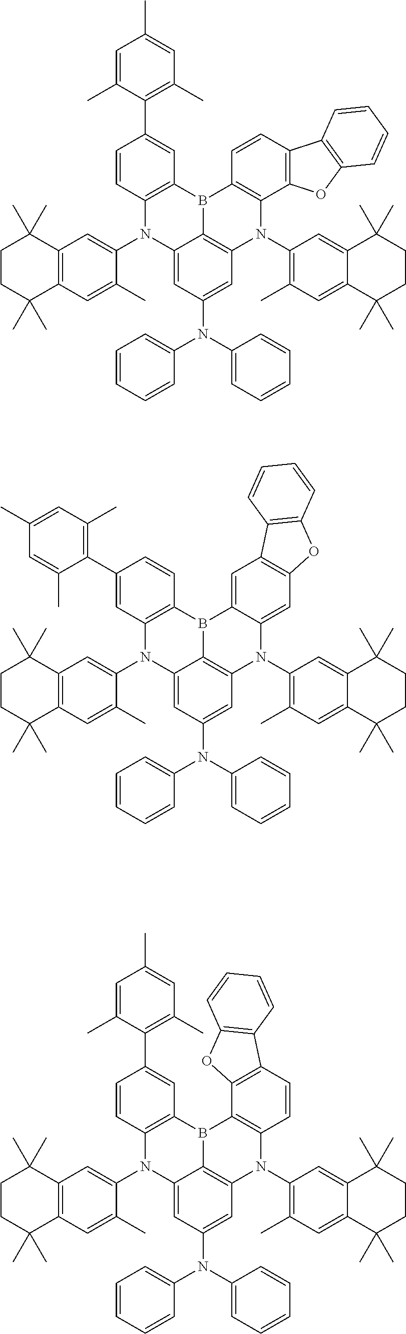 [SMILES: Cc1cc(C)c(-c2ccc3c(c2)B2c4ccc5c(oc6ccccc65)c4N(c4cc5c(cc4C)C(C)(C)CCC5(C)C)c4cc(N(c5ccccc5)c5ccccc5)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(N(c4ccccc4)c4ccccc4)cc4c2B3c2cc3c(cc2N4c2cc4c(cc2C)C(C)(C)CCC4(C)C)oc2ccccc23)c(C)c1 ; Cc1cc(C)c(-c2ccc3c(c2)B2c4c(cc(N(c5ccccc5)c5ccccc5)cc4N(c4cc5c(cc4C)C(C)(C)CCC5(C)C)c4ccc5c(oc6ccccc65)c42)N3c2cc3c(cc2C)C(C)(C)CCC3(C)C)c(C)c1]

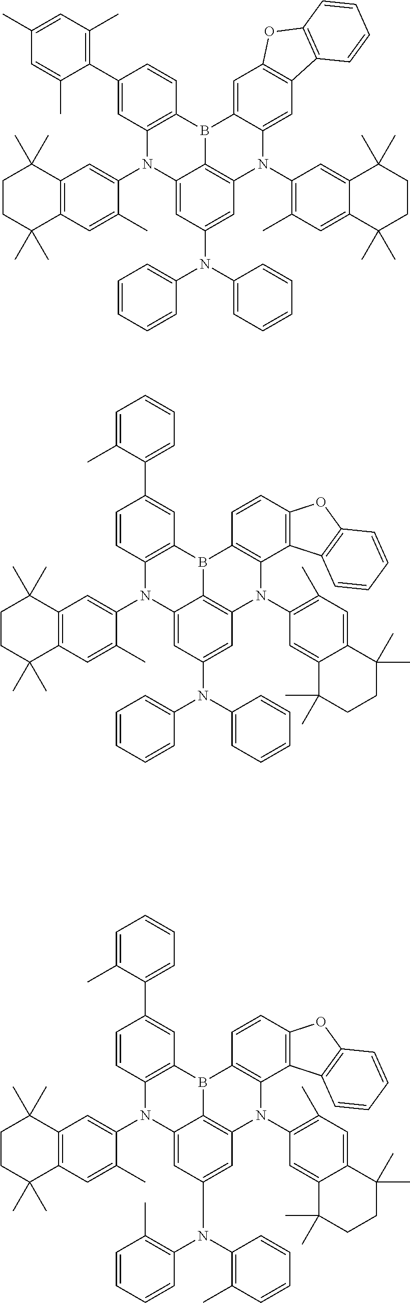 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3oc5ccccc5c3cc2N4c2cc3c(cc2C)C(C)(C)CCC3(C)C)c(C)c1 ; Cc1ccccc1-c1ccc2c(c1)B1c3ccc4oc5ccccc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C ; Cc1ccccc1-c1ccc2c(c1)B1c3ccc4oc5ccccc5c4c3N(c3cc4c(cc3C)C(C)(C)CCC4(C)C)c3cc(N(c4ccccc4C)c4ccccc4C)cc(c31)N2c1cc2c(cc1C)C(C)(C)CCC2(C)C]

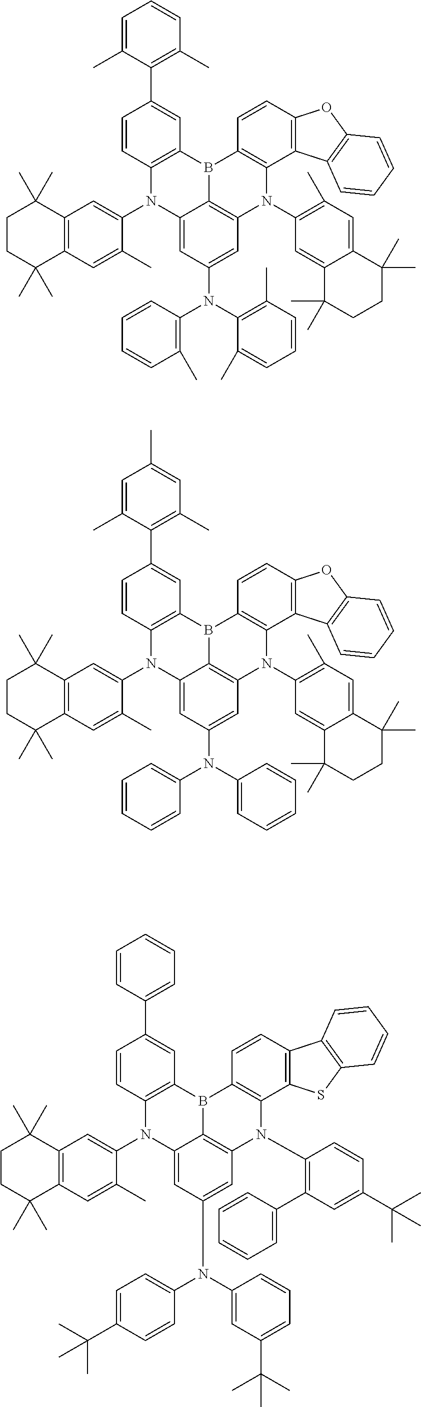 [SMILES: Cc1cc2c(cc1N1c3ccc(-c4c(C)cccc4C)cc3B3c4ccc5oc6ccccc6c5c4N(c4cc5c(cc4C)C(C)(C)CCC5(C)C)c4cc(N(c5ccccc5C)c5c(C)cccc5C)cc1c43)C(C)(C)CCC2(C)C ; Cc1cc(C)c(-c2ccc3c(c2)B2c4ccc5oc6ccccc6c5c4N(c4cc5c(cc4C)C(C)(C)CCC5(C)C)c4cc(N(c5ccccc5)c5ccccc5)cc(c42)N3c2cc3c(cc2C)C(C)(C)CCC3(C)C)c(C)c1 ; Cc1cc2c(cc1N1c3ccc(-c4ccccc4)cc3B3c4ccc5c(sc6ccccc65)c4N(c4ccc(C(C)(C)C)cc4-c4ccccc4)c4cc(N(c5ccc(C(C)(C)C)cc5)c5cccc(C(C)(C)C)c5)cc1c43)C(C)(C)CCC2(C)C]

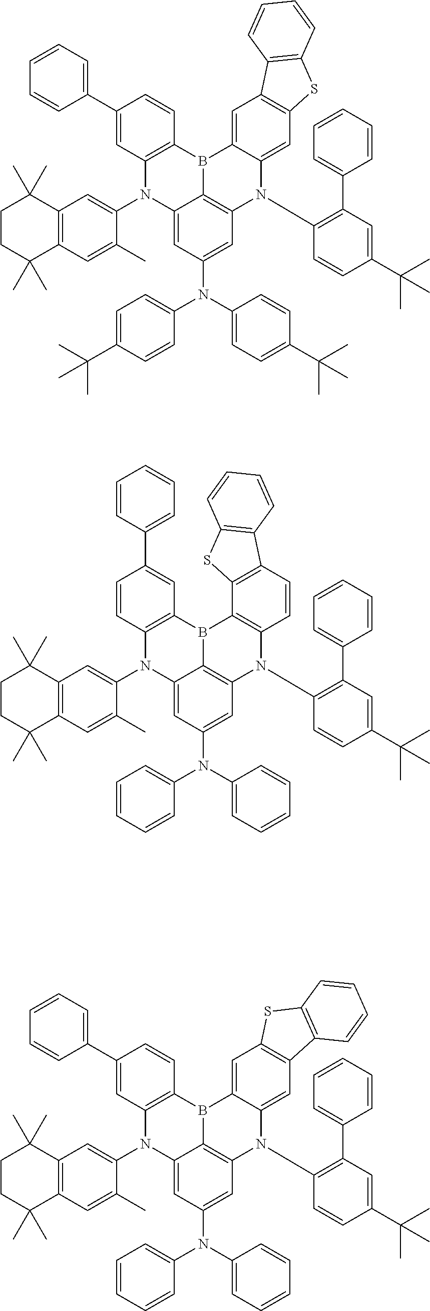 [SMILES: Cc1cc2c(cc1N1c3cc(-c4ccccc4)ccc3B3c4cc5c(cc4N(c4ccc(C(C)(C)C)cc4-c4ccccc4)c4cc(N(c6ccc(C(C)(C)C)cc6)c6ccc(C(C)(C)C)cc6)cc1c43)sc1ccccc15)C(C)(C)CCC2(C)C ; Cc1cc2c(cc1N1c3ccc(-c4ccccc4)cc3B3c4c1cc(N(c1ccccc1)c1ccccc1)cc4N(c1ccc(C(C)(C)C)cc1-c1ccccc1)c1ccc4c(sc5ccccc54)c13)C(C)(C)CCC2(C)C ; Cc1cc2c(cc1N1c3cc(-c4ccccc4)ccc3B3c4cc5sc6ccccc6c5cc4N(c4ccc(C(C)(C)C)cc4-c4ccccc4)c4cc(N(c5ccccc5)c5ccccc5)cc1c43)C(C)(C)CCC2(C)C]

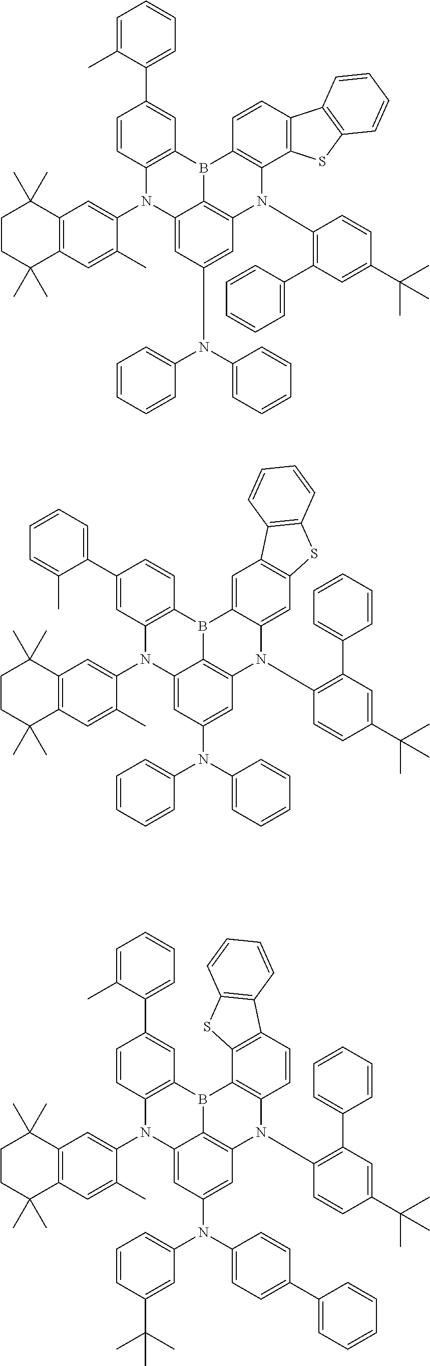 [SMILES: Cc1ccccc1-c1ccc2c(c1)B1c3ccc4c(sc5ccccc54)c3N(c3ccc(C(C)(C)C)cc3-c3ccccc3)c3cc(N(c4ccccc4)c4ccccc4)cc(c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2c(cc1N3c1ccc(C(C)(C)C)cc1-c1ccccc1)sc1ccccc12 ; Cc1ccccc1-c1ccc2c(c1)B1c3c(cc(N(c4ccc(-c5ccccc5)cc4)c4cccc(C(C)(C)C)c4)cc3N(c3ccc(C(C)(C)C)cc3-c3ccccc3)c3ccc4c(sc5ccccc54)c31)N2c1cc2c(cc1C)C(C)(C)CCC2(C)C]

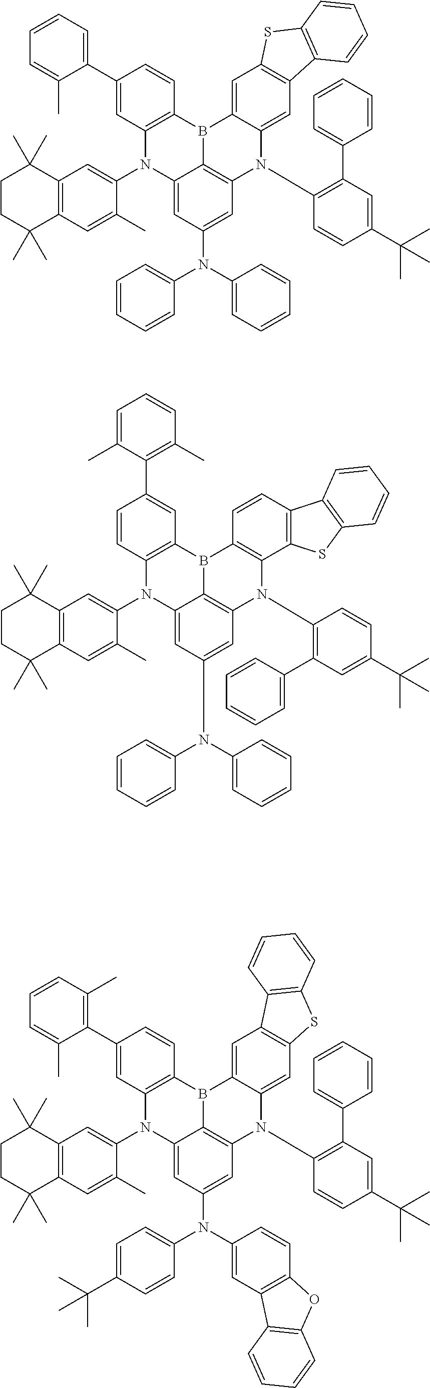 [SMILES: Cc1ccccc1-c1ccc2c(c1)N(c1cc3c(cc1C)C(C)(C)CCC3(C)C)c1cc(N(c3ccccc3)c3ccccc3)cc3c1B2c1cc2sc4ccccc4c2cc1N3c1ccc(C(C)(C)C)cc1-c1ccccc1 ; Cc1cc2c(cc1N1c3ccc(-c4c(C)cccc4C)cc3B3c4ccc5c(sc6ccccc65)c4N(c4ccc(C(C)(C)C)cc4-c4ccccc4)c4cc(N(c5ccccc5)c5ccccc5)cc1c43)C(C)(C)CCC2(C)C ; Cc1cc2c(cc1N1c3cc(-c4c(C)cccc4C)ccc3B3c4cc5c(cc4N(c4ccc(C(C)(C)C)cc4-c4ccccc4)c4cc(N(c6ccc(C(C)(C)C)cc6)c6ccc7oc8ccccc8c7c6)cc1c43)sc1ccccc15)C(C)(C)CCC2(C)C]

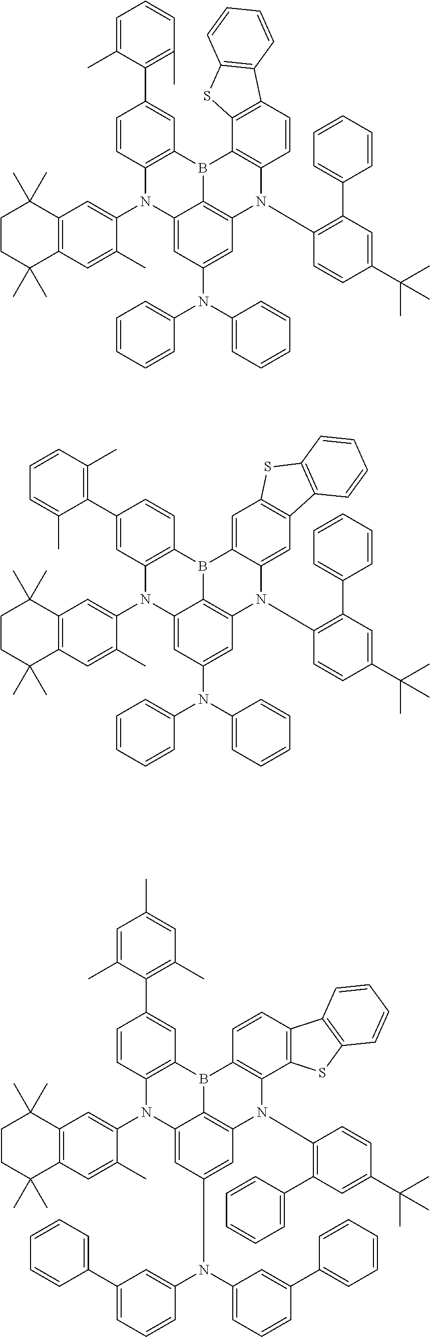 [SMILES: Cc1cc2c(cc1N1c3ccc(-c4c(C)cccc4C)cc3B3c4c1cc(N(c1ccccc1)c1ccccc1)cc4N(c1ccc(C(C)(C)C)cc1-c1ccccc1)c1ccc4c(sc5ccccc54)c13)C(C)(C)CCC2(C)C ; Cc1cc2c(cc1N1c3cc(-c4c(C)cccc4C)ccc3B3c4cc5sc6ccccc6c5cc4N(c4ccc(C(C)(C)C)cc4-c4ccccc4)c4cc(N(c5ccccc5)c5ccccc5)cc1c43)C(C)(C)CCC2(C)C ; Cc1cc(C)c(-c2ccc3c(c2)B2c4ccc5c(sc6ccccc65)c4N(c4ccc(C(C)(C)C)cc4-c4ccccc4)c4cc(N(c5cccc(-c6ccccc6)c5)c5cccc(-c6ccccc6)c5)cc(c42)N3c2cc3c(cc2C)C(C)(C)CCC3(C)C)c(C)c1]

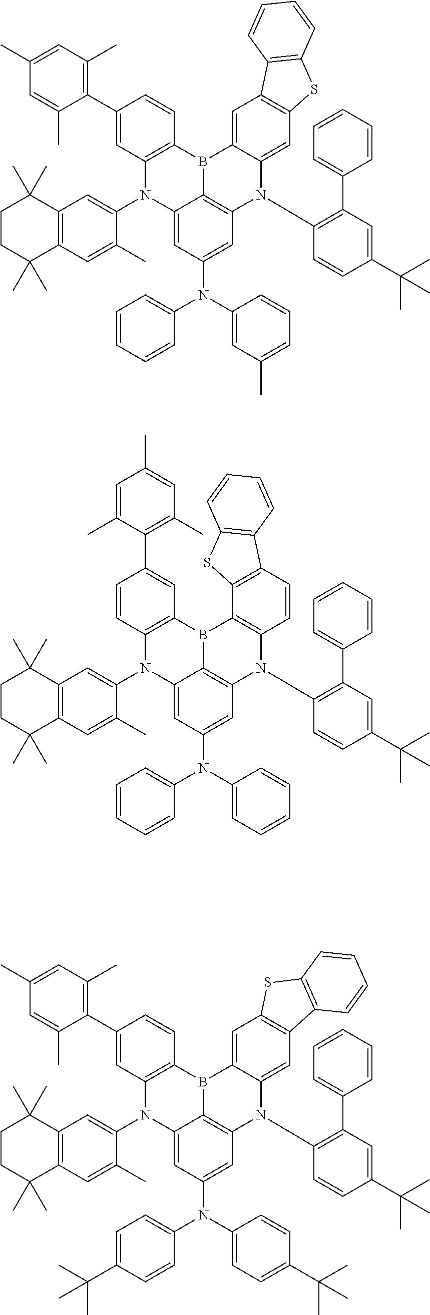 [SMILES: Cc1cccc(N(c2ccccc2)c2cc3c4c(c2)N(c2ccc(C(C)(C)C)cc2-c2ccccc2)c2cc5sc6ccccc6c5cc2B4c2ccc(-c4c(C)cc(C)cc4C)cc2N3c2cc3c(cc2C)C(C)(C)CCC3(C)C)c1 ; Cc1cc(C)c(-c2ccc3c(c2)B2c4c(cc(N(c5ccccc5)c5ccccc5)cc4N(c4ccc(C(C)(C)C)cc4-c4ccccc4)c4ccc5c(sc6ccccc65)c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(N(c4ccc(C(C)(C)C)cc4)c4ccc(C(C)(C)C)cc4)cc4c2B3c2cc3sc5ccccc5c3cc2N4c2ccc(C(C)(C)C)cc2-c2ccccc2)c(C)c1]

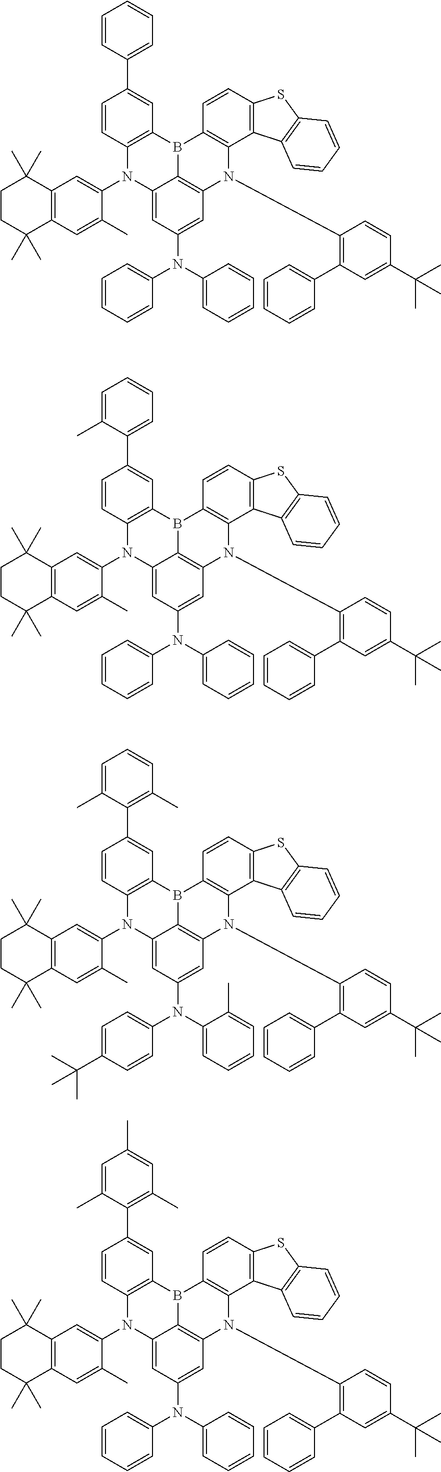

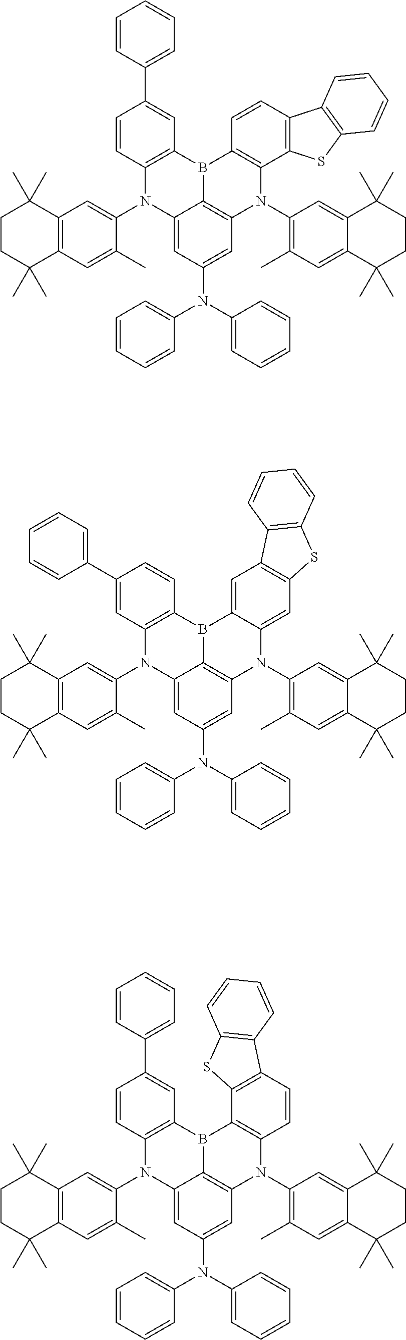 [SMILES: Cc1cc2c(cc1N1c3ccc(-c4ccccc4)cc3B3c4ccc5c(sc6ccccc65)c4N(c4cc5c(cc4C)C(C)(C)CCC5(C)C)c4cc(N(c5ccccc5)c5ccccc5)cc1c43)C(C)(C)CCC2(C)C ; Cc1cc2c(cc1N1c3cc(-c4ccccc4)ccc3B3c4cc5c(cc4N(c4cc6c(cc4C)C(C)(C)CCC6(C)C)c4cc(N(c6ccccc6)c6ccccc6)cc1c43)sc1ccccc15)C(C)(C)CCC2(C)C ; Cc1cc2c(cc1N1c3ccc(-c4ccccc4)cc3B3c4c1cc(N(c1ccccc1)c1ccccc1)cc4N(c1cc4c(cc1C)C(C)(C)CCC4(C)C)c1ccc4c(sc5ccccc54)c13)C(C)(C)CCC2(C)C]

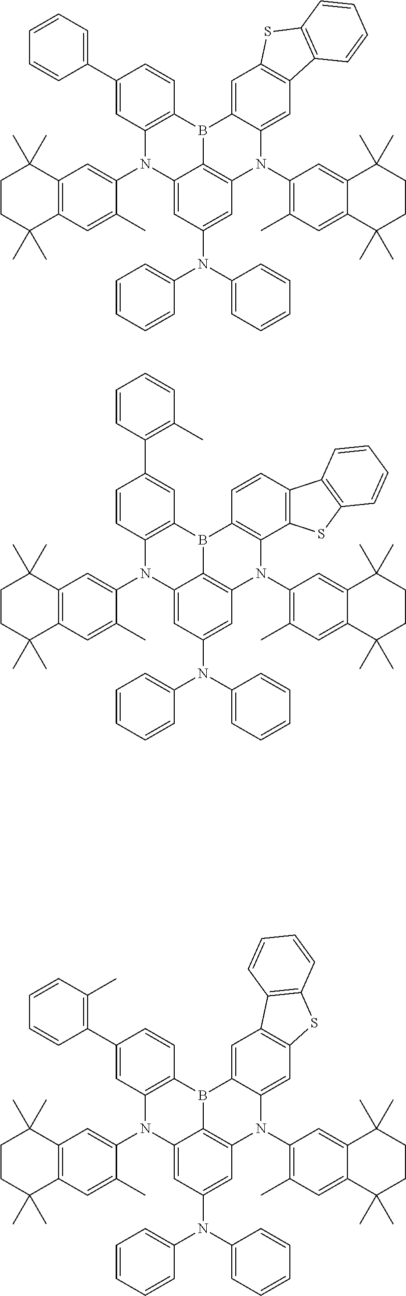

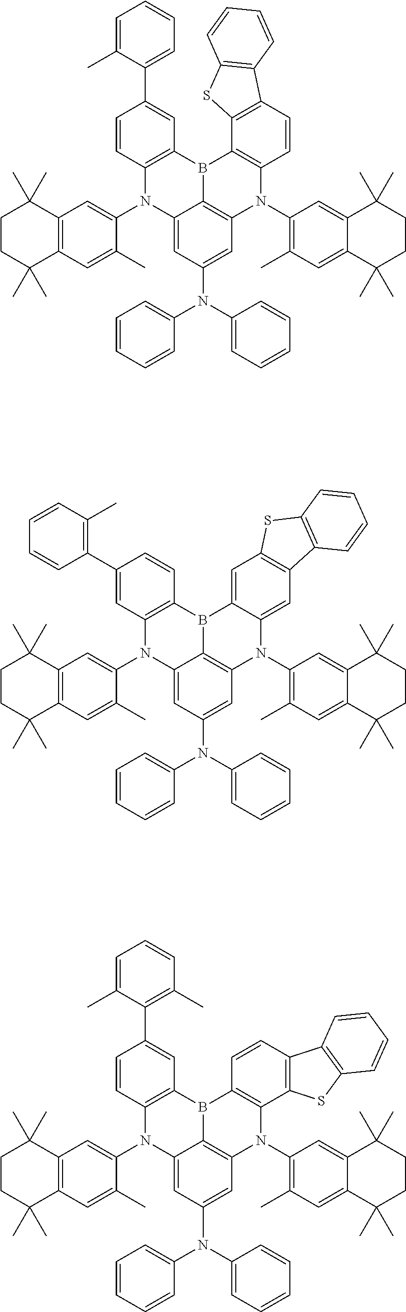 [SMILES: Cc1ccccc1-c1ccc2c(c1)B1c3c(cc(N(c4ccccc4)c4ccccc4)cc3N(c3cc4c(cc3C)C(C)(C)CCC4(C)C)c3ccc4c(sc5ccccc54)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2sc4ccccc4c2cc1N3c1cc2c(cc1C)C(C)(C)CCC2(C)C ; Cc1cc2c(cc1N1c3ccc(-c4c(C)cccc4C)cc3B3c4ccc5c(sc6ccccc65)c4N(c4cc5c(cc4C)C(C)(C)CCC5(C)C)c4cc(N(c5ccccc5)c5ccccc5)cc1c43)C(C)(C)CCC2(C)C]

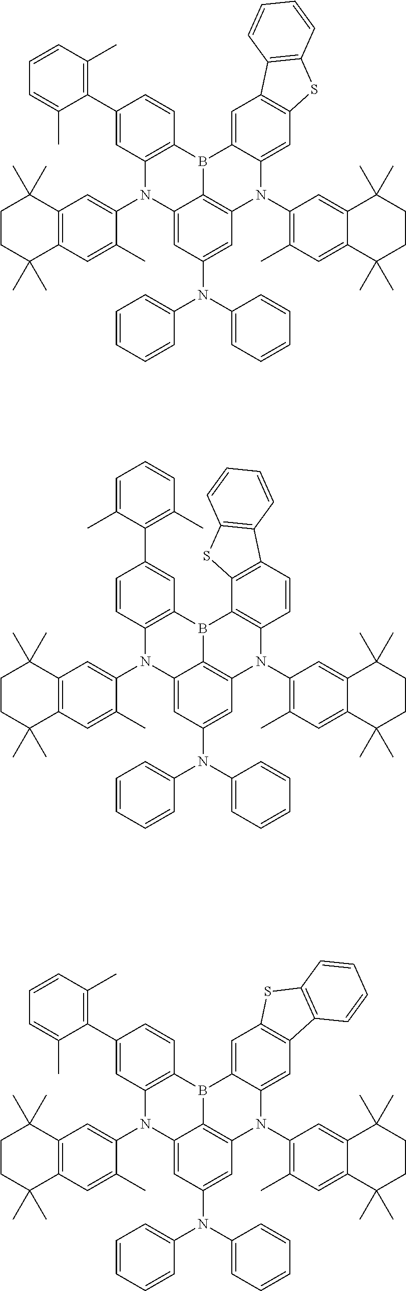 [SMILES: Cc1cc2c(cc1N1c3cc(-c4c(C)cccc4C)ccc3B3c4cc5c(cc4N(c4cc6c(cc4C)C(C)(C)CCC6(C)C)c4cc(N(c6ccccc6)c6ccccc6)cc1c43)sc1ccccc15)C(C)(C)CCC2(C)C ; Cc1cc2c(cc1N1c3ccc(-c4c(C)cccc4C)cc3B3c4c1cc(N(c1ccccc1)c1ccccc1)cc4N(c1cc4c(cc1C)C(C)(C)CCC4(C)C)c1ccc4c(sc5ccccc54)c13)C(C)(C)CCC2(C)C ; Cc1cc2c(cc1N1c3cc(-c4c(C)cccc4C)ccc3B3c4cc5sc6ccccc6c5cc4N(c4cc5c(cc4C)C(C)(C)CCC5(C)C)c4cc(N(c5ccccc5)c5ccccc5)cc1c43)C(C)(C)CCC2(C)C]

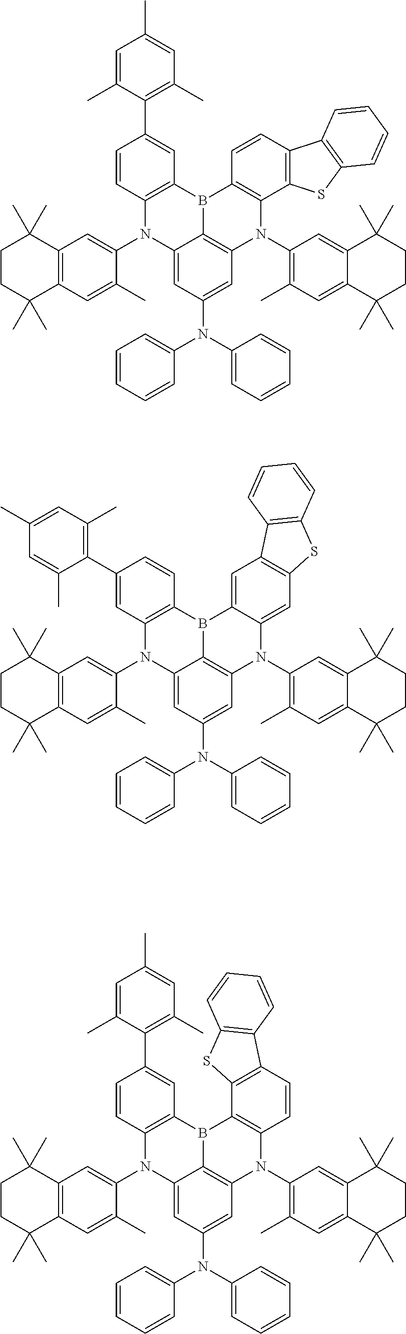 [SMILES: Cc1cc(C)c(-c2ccc3c(c2)B2c4ccc5c(sc6ccccc65)c4N(c4cc5c(cc4C)C(C)(C)CCC5(C)C)c4cc(N(c5ccccc5)c5ccccc5)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(N(c4ccccc4)c4ccccc4)cc4c2B3c2cc3c(cc2N4c2cc4c(cc2C)C(C)(C)CCC4(C)C)sc2ccccc23)c(C)c1 ; Cc1cc(C)c(-c2ccc3c(c2)B2c4c(cc(N(c5ccccc5)c5ccccc5)cc4N(c4cc5c(cc4C)C(C)(C)CCC5(C)C)c4ccc5c(sc6ccccc65)c42)N3c2cc3c(cc2C)C(C)(C)CCC3(C)C)c(C)c1]

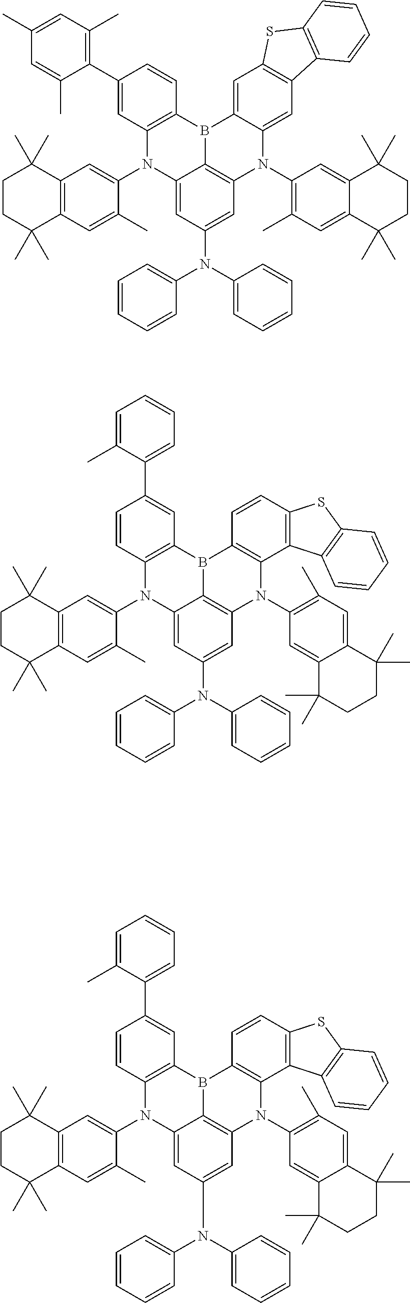 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3sc5ccccc5c3cc2N4c2cc3c(cc2C)C(C)(C)CCC3(C)C)c(C)c1 ; Cc1ccccc1-c1ccc2c(c1)B1c3ccc4sc5ccccc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C ; Cc1ccccc1-c1ccc2c(c1)B1c3ccc4sc5ccccc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C]

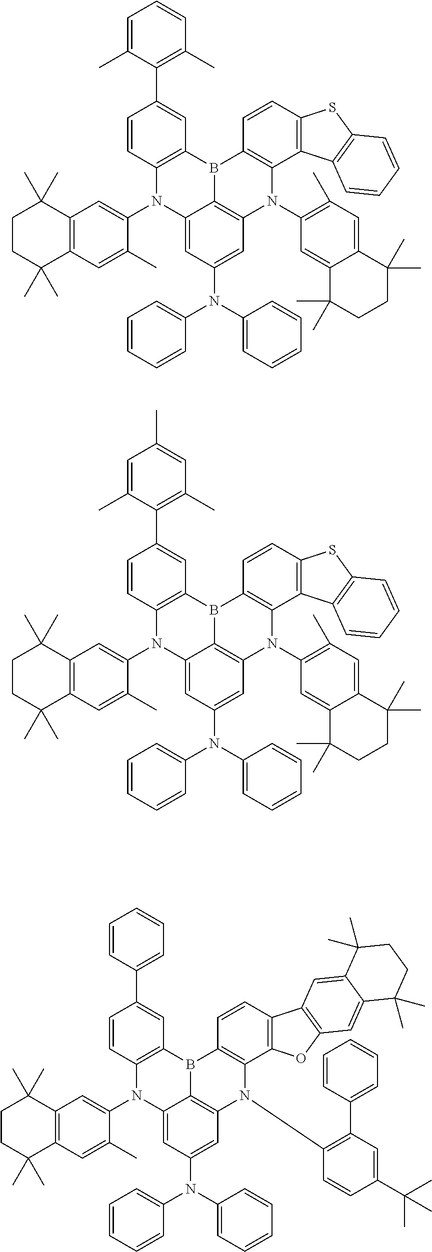

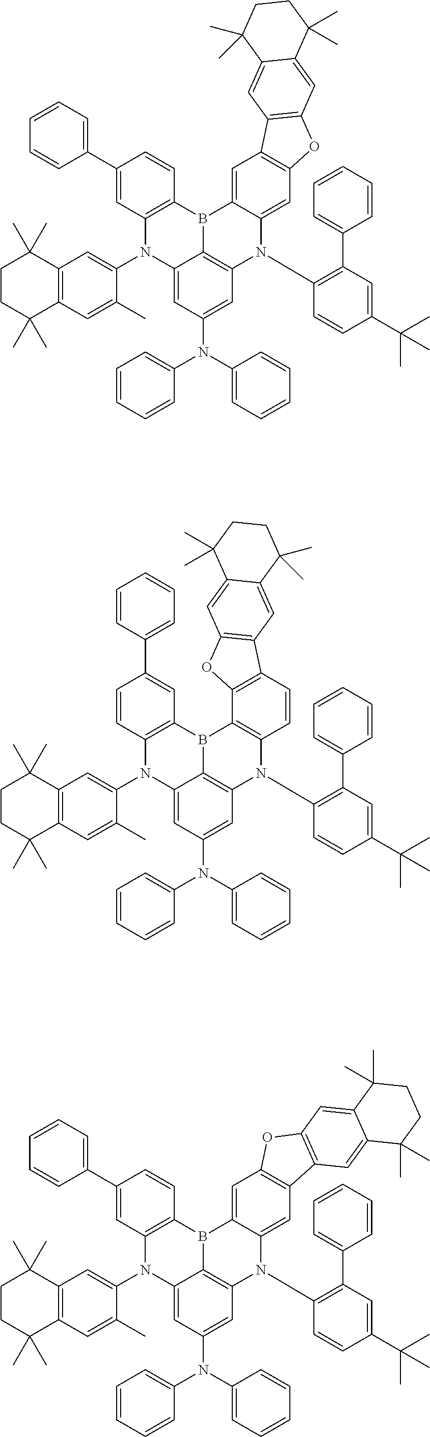 [SMILES: Cc1cc2c(cc1N1c3cc(-c4ccccc4)ccc3B3c4cc5c(cc4N(c4ccc(C(C)(C)C)cc4-c4ccccc4)c4cc(N(c6ccccc6)c6ccccc6)cc1c43)oc1cc3c(cc15)C(C)(C)CCC3(C)C)C(C)(C)CCC2(C)C ; Cc1cc2c(cc1N1c3ccc(-c4ccccc4)cc3B3c4c1cc(N(c1ccccc1)c1ccccc1)cc4N(c1ccc(C(C)(C)C)cc1-c1ccccc1)c1ccc4c(oc5cc6c(cc54)C(C)(C)CCC6(C)C)c13)C(C)(C)CCC2(C)C ; Cc1cc2c(cc1N1c3cc(-c4ccccc4)ccc3B3c4cc5oc6cc7c(cc6c5cc4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C]

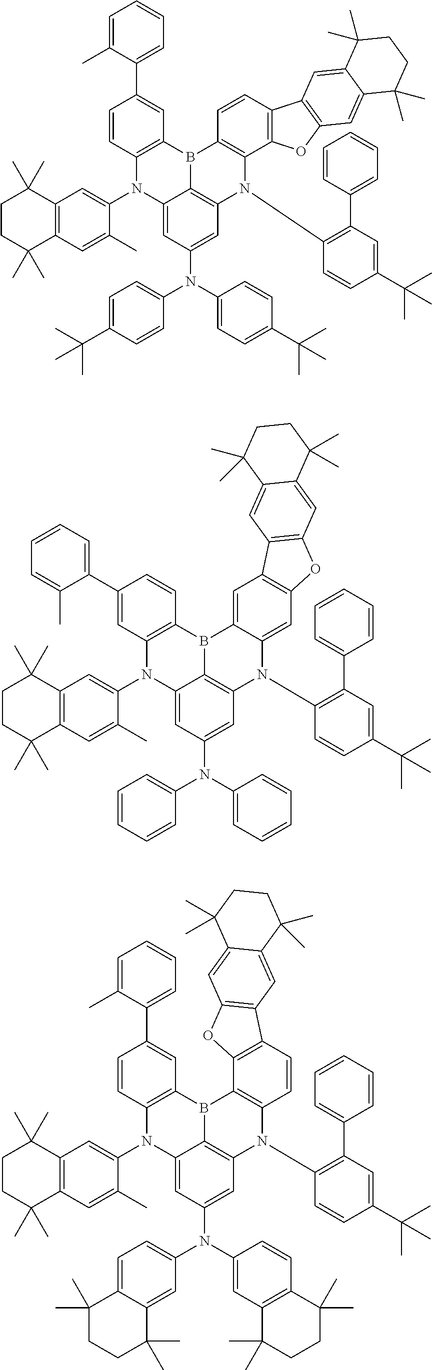

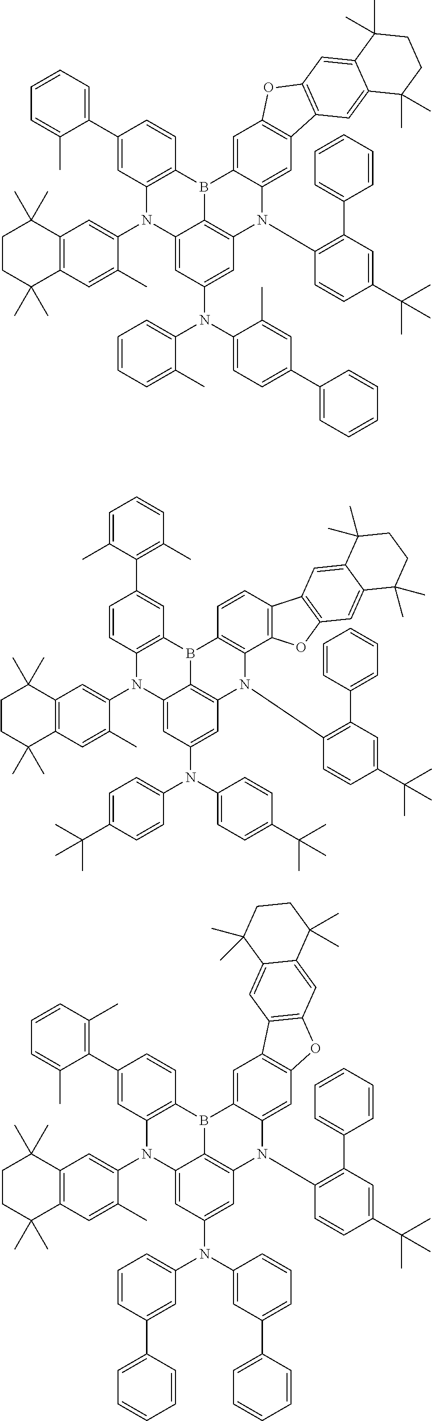

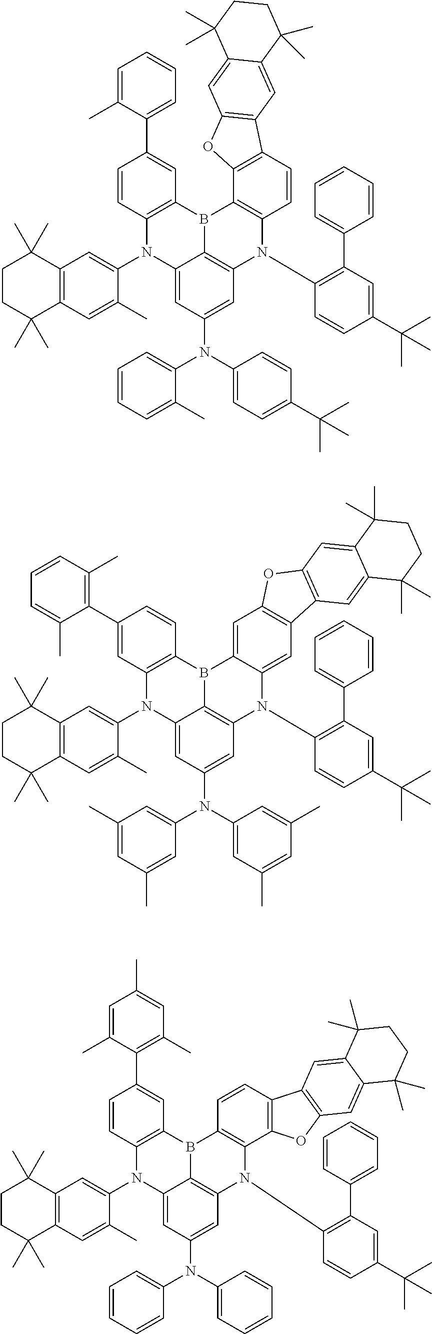 [SMILES: Cc1ccccc1-c1ccc2c(c1)B1c3c(cc(N(c4ccc(C(C)(C)C)cc4)c4ccccc4C)cc3N(c3ccc(C(C)(C)C)cc3-c3ccccc3)c3ccc4c(oc5cc6c(cc54)C(C)(C)CCC6(C)C)c31)N2c1cc2c(cc1C)C(C)(C)CCC2(C)C ; Cc1cc(C)cc(N(c2cc(C)cc(C)c2)c2cc3c4c(c2)N(c2ccc(C(C)(C)C)cc2-c2ccccc2)c2cc5c(cc2B4c2ccc(-c4c(C)cccc4C)cc2N3c2cc3c(cc2C)C(C)(C)CCC3(C)C)oc2cc3c(cc25)C(C)(C)CCC3(C)C)c1 ; Cc1cc(C)c(-c2ccc3c(c2)B2c4ccc5c(oc6cc7c(cc65)C(C)(C)CCC7(C)C)c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)c(C)c1]

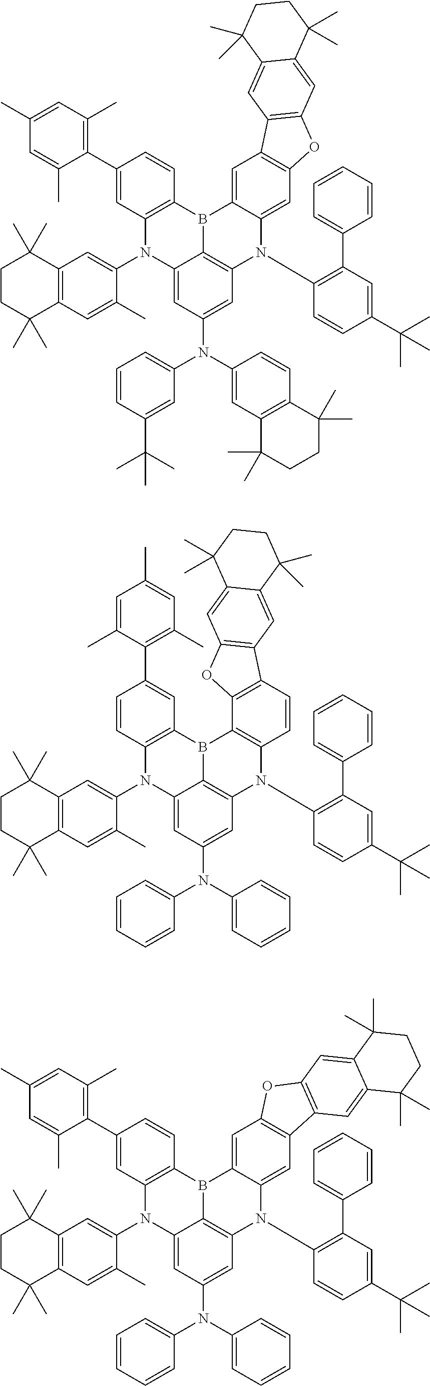

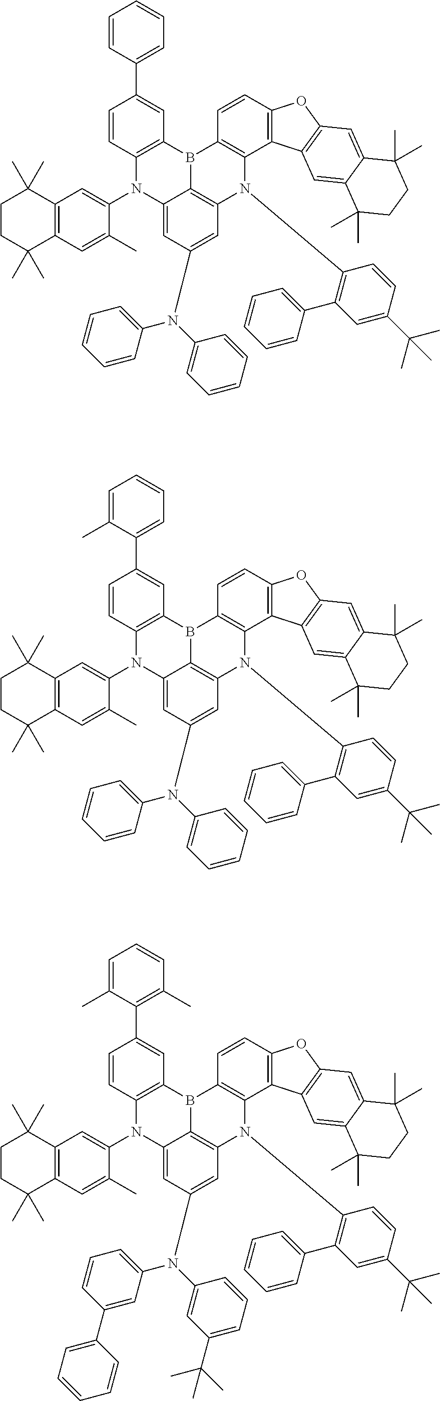 [SMILES: Cc1cc2c(cc1N1c3ccc(-c4ccccc4)cc3B3c4ccc5oc6cc7c(cc6c5c4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1ccccc1-c1ccc2c(c1)B1c3ccc4oc5cc6c(cc5c4c3N(c3ccc(C(C)(C)C)cc3-c3ccccc3)c3cc(N(c4ccccc4)c4ccccc4)cc(c31)N2c1cc2c(cc1C)C(C)(C)CCC2(C)C)C(C)(C)CCC6(C)C ; Cc1cc2c(cc1N1c3ccc(-c4c(C)cccc4C)cc3B3c4ccc5oc6cc7c(cc6c5c4N(c4ccc(C(C)(C)C)cc4-c4ccccc4)c4cc(N(c5cccc(-c6ccccc6)c5)c5cccc(C(C)(C)C)c5)cc1c43)C(C)(C)CCC7(C)C)C(C)(C)CCC2(C)C]

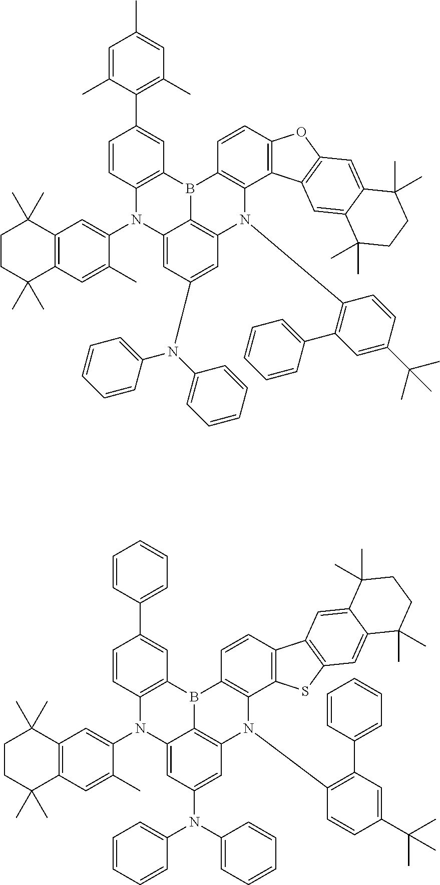 [SMILES: Cc1cc(C)c(-c2ccc3c(c2)B2c4ccc5oc6cc7c(cc6c5c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)C(C)(C)CCC7(C)C)c(C)c1 ; Cc1cc2c(cc1N1c3ccc(-c4ccccc4)cc3B3c4ccc5c(sc6cc7c(cc65)C(C)(C)CCC7(C)C)c4N(c4ccc(C(C)(C)C)cc4-c4ccccc4)c4cc(N(c5ccccc5)c5ccccc5)cc1c43)C(C)(C)CCC2(C)C]

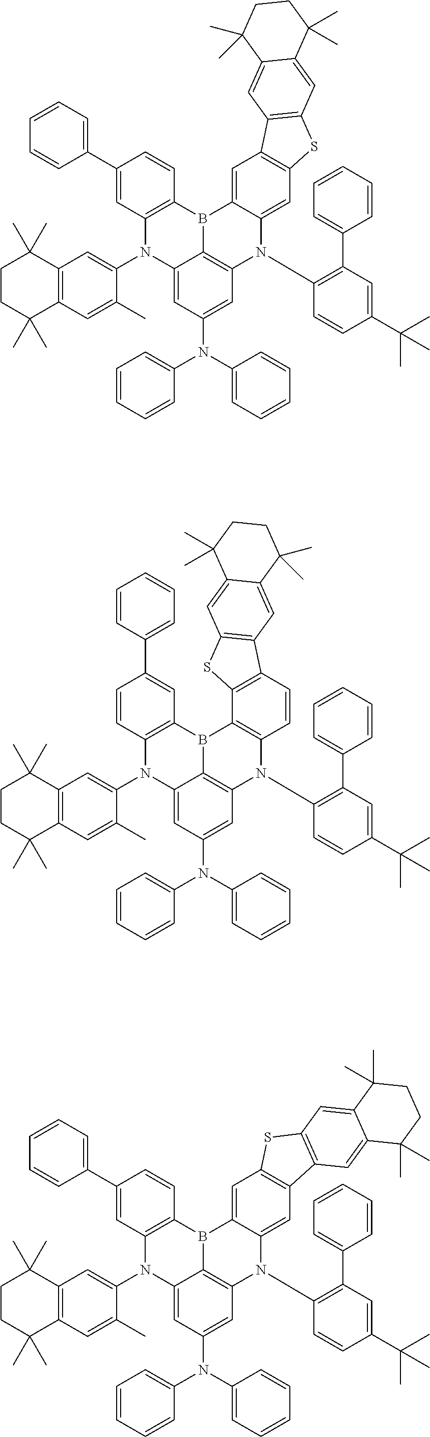 [SMILES: Cc1cc2c(cc1N1c3cc(-c4ccccc4)ccc3B3c4cc5c(cc4N(c4ccc(C(C)(C)C)cc4-c4ccccc4)c4cc(N(c6ccccc6)c6ccccc6)cc1c43)sc1cc3c(cc15)C(C)(C)CCC3(C)C)C(C)(C)CCC2(C)C ; Cc1cc2c(cc1N1c3ccc(-c4ccccc4)cc3B3c4c1cc(N(c1ccccc1)c1ccccc1)cc4N(c1ccc(C(C)(C)C)cc1-c1ccccc1)c1ccc4c(sc5cc6c(cc54)C(C)(C)CCC6(C)C)c13)C(C)(C)CCC2(C)C ; Cc1cc2c(cc1N1c3cc(-c4ccccc4)ccc3B3c4cc5sc6cc7c(cc6c5cc4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C]

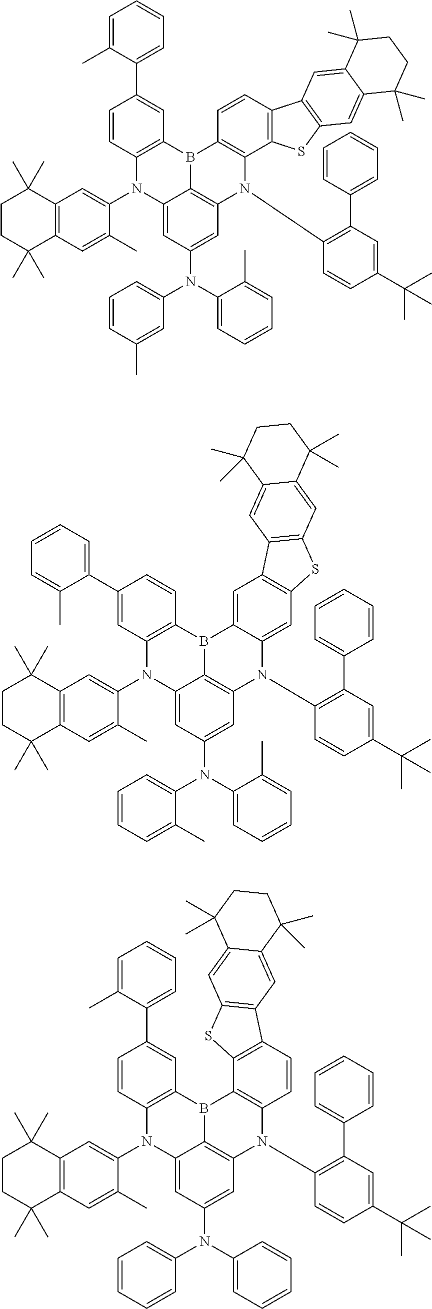 [SMILES: Cc1cccc(N(c2cc3c4c(c2)N(c2ccc(C(C)(C)C)cc2-c2ccccc2)c2c(ccc5c2sc2cc6c(cc25)C(C)(C)CCC6(C)C)B4c2cc(-c4ccccc4C)ccc2N3c2cc3c(cc2C)C(C)(C)CCC3(C)C)c2ccccc2C)c1 ; Cc1ccccc1-c1ccc2c(c1)N(c1cc3c(cc1C)C(C)(C)CCC3(C)C)c1cc(N(c3ccccc3C)c3ccccc3C)cc3c1B2c1cc2c(cc1N3c1ccc(C(C)(C)C)cc1-c1ccccc1)sc1cc3c(cc12)C(C)(C)CCC3(C)C ; Cc1ccccc1-c1ccc2c(c1)B1c3c(cc(N(c4ccccc4)c4ccccc4)cc3N(c3ccc(C(C)(C)C)cc3-c3ccccc3)c3ccc4c(sc5cc6c(cc54)C(C)(C)CCC6(C)C)c31)N2c1cc2c(cc1C)C(C)(C)CCC2(C)C]

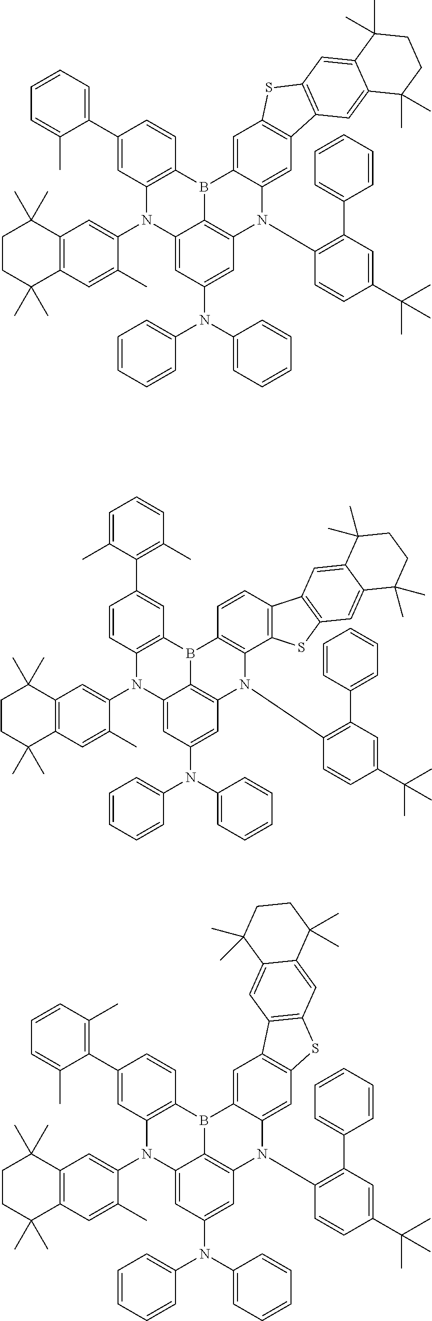 [SMILES: Cc1ccccc1-c1ccc2c(c1)N(c1cc3c(cc1C)C(C)(C)CCC3(C)C)c1cc(N(c3ccccc3)c3ccccc3)cc3c1B2c1cc2sc4cc5c(cc4c2cc1N3c1ccc(C(C)(C)C)cc1-c1ccccc1)C(C)(C)CCC5(C)C ; Cc1cc2c(cc1N1c3ccc(-c4c(C)cccc4C)cc3B3c4ccc5c(sc6cc7c(cc65)C(C)(C)CCC7(C)C)c4N(c4ccc(C(C)(C)C)cc4-c4ccccc4)c4cc(N(c5ccccc5)c5ccccc5)cc1c43)C(C)(C)CCC2(C)C ; Cc1cc2c(cc1N1c3cc(-c4c(C)cccc4C)ccc3B3c4cc5c(cc4N(c4ccc(C(C)(C)C)cc4-c4ccccc4)c4cc(N(c6ccccc6)c6ccccc6)cc1c43)sc1cc3c(cc15)C(C)(C)CCC3(C)C)C(C)(C)CCC2(C)C]

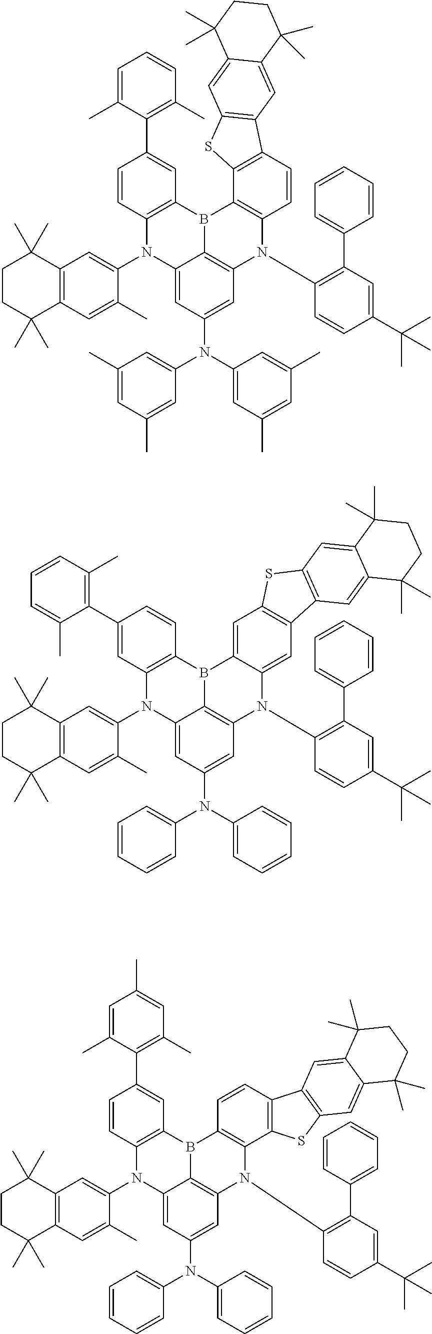 [SMILES: Cc1cc(C)cc(N(c2cc(C)cc(C)c2)c2cc3c4c(c2)N(c2ccc(C(C)(C)C)cc2-c2ccccc2)c2ccc5c(sc6cc7c(cc65)C(C)(C)CCC7(C)C)c2B4c2cc(-c4c(C)cccc4C)ccc2N3c2cc3c(cc2C)C(C)(C)CCC3(C)C)c1 ; Cc1cc2c(cc1N1c3cc(-c4c(C)cccc4C)ccc3B3c4cc5sc6cc7c(cc6c5cc4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1cc(C)c(-c2ccc3c(c2)B2c4ccc5c(sc6cc7c(cc65)C(C)(C)CCC7(C)C)c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)c(C)c1]

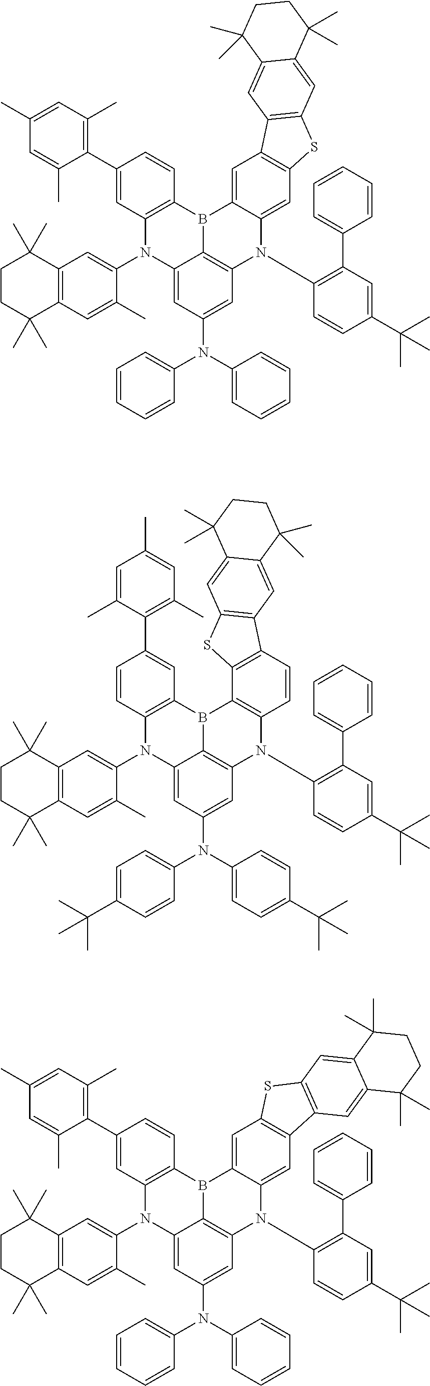

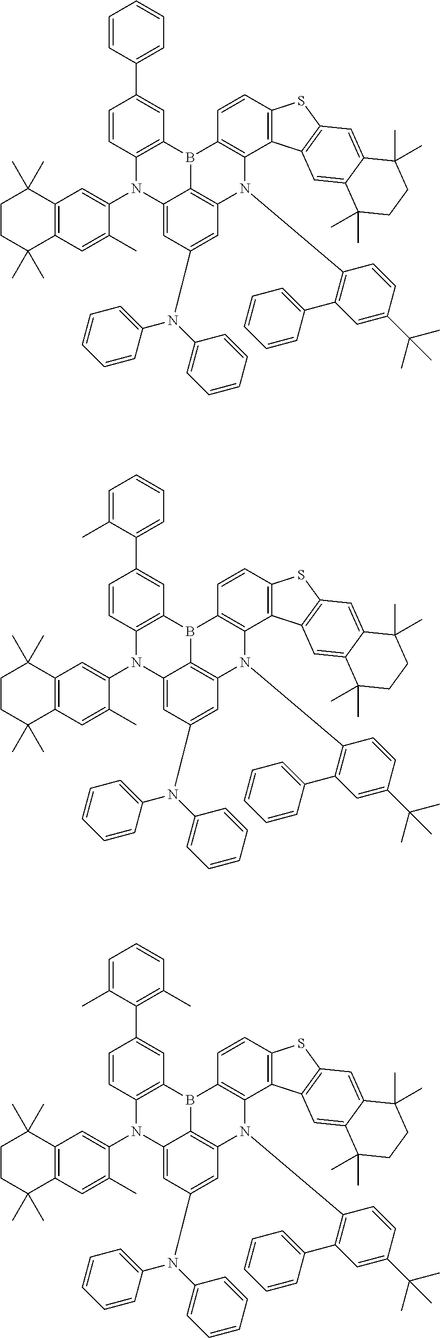 [SMILES: Cc1cc2c(cc1N1c3ccc(-c4ccccc4)cc3B3c4ccc5sc6cc7c(cc6c5c4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1ccccc1-c1ccc2c(c1)B1c3ccc4sc5cc6c(cc5c4c3N(c3ccc(C(C)(C)C)cc3-c3ccccc3)c3cc(N(c4ccccc4)c4ccccc4)cc(c31)N2c1cc2c(cc1C)C(C)(C)CCC2(C)C)C(C)(C)CCC6(C)C ; Cc1cc2c(cc1N1c3ccc(-c4c(C)cccc4C)cc3B3c4ccc5sc6cc7c(cc6c5c4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C]

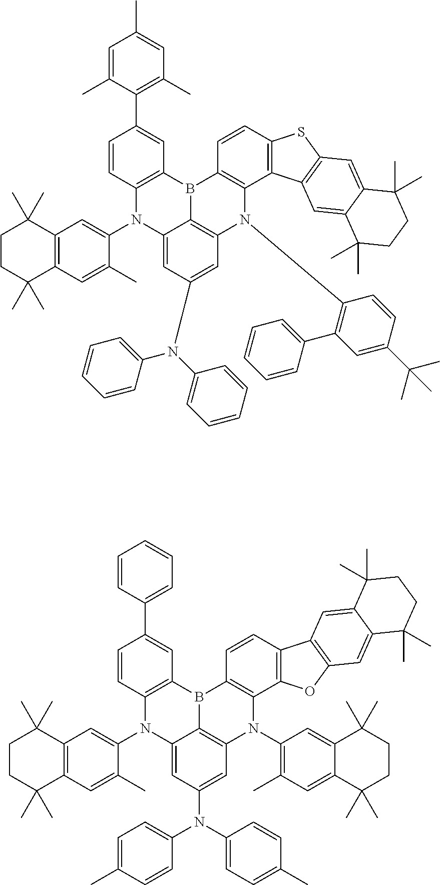

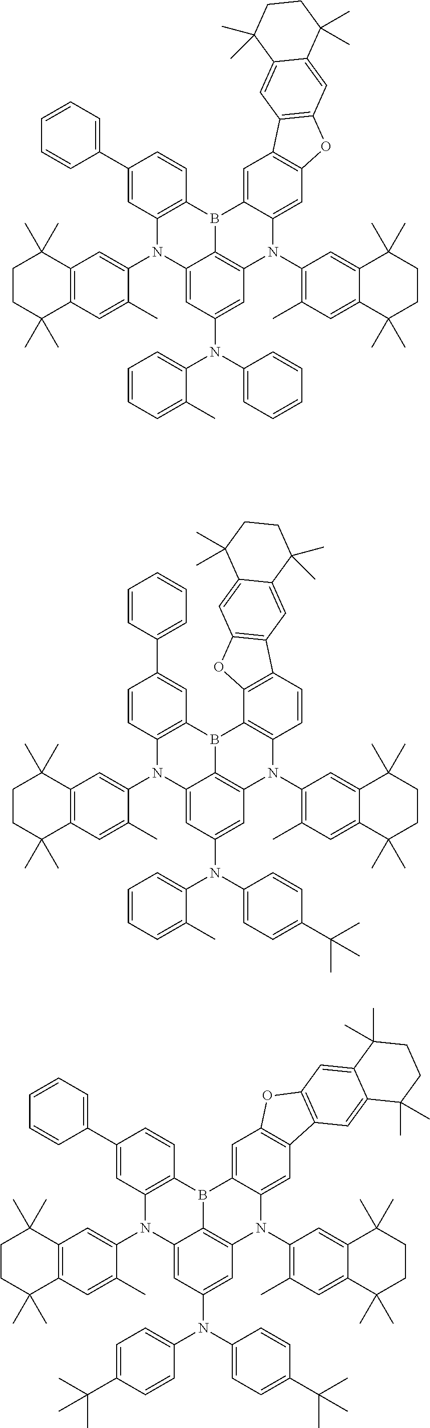

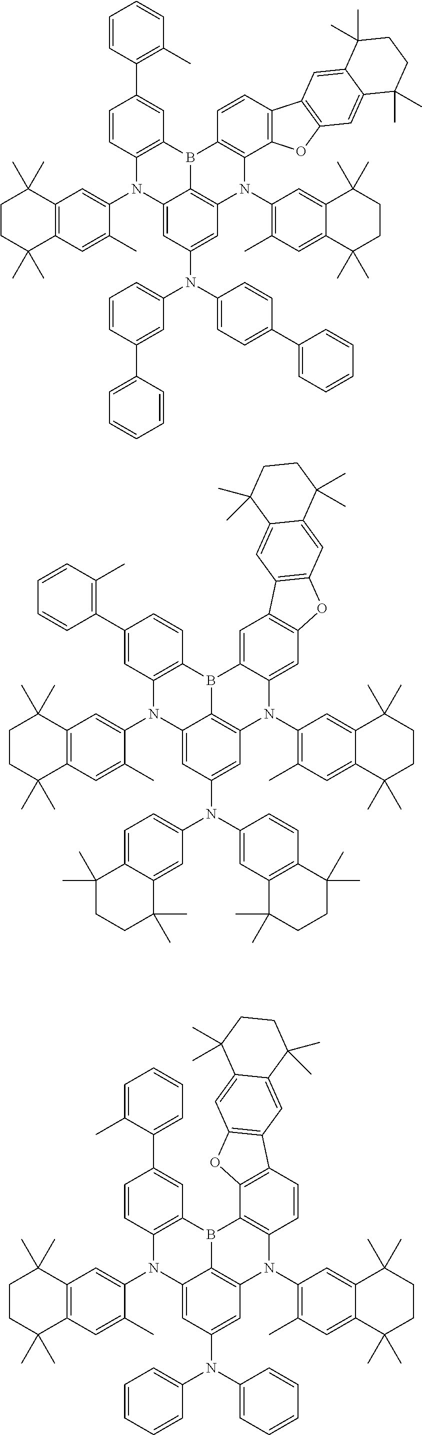

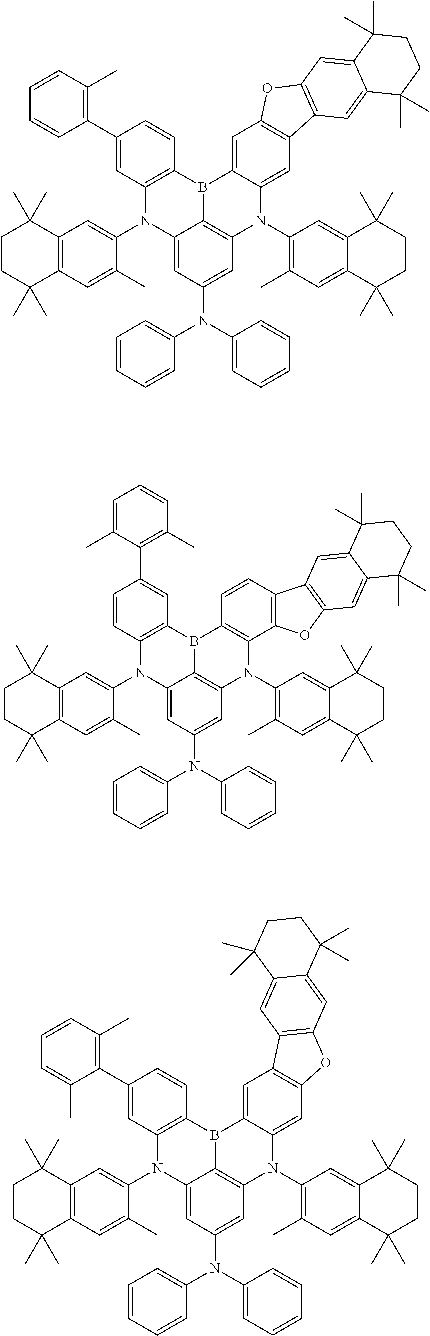

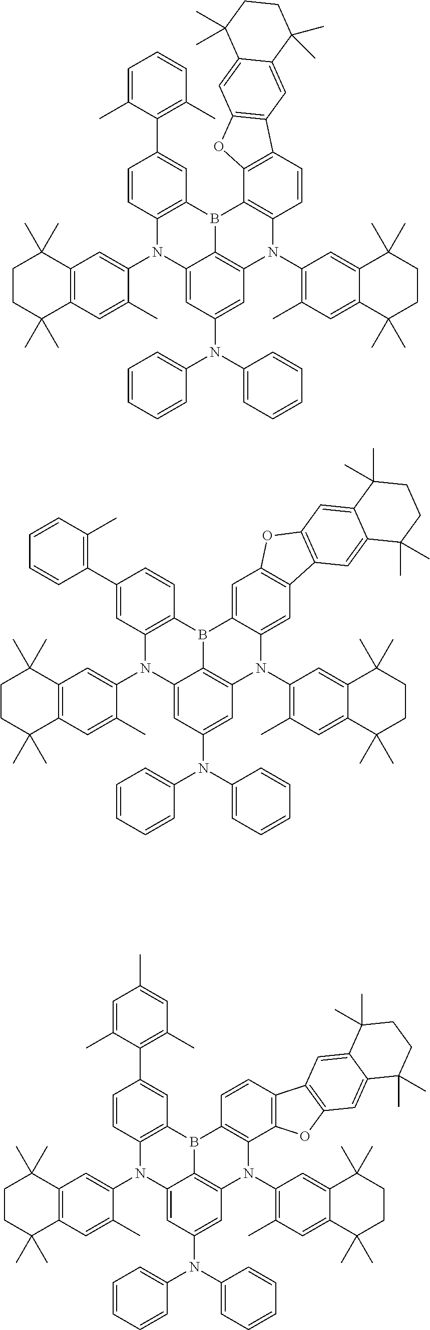

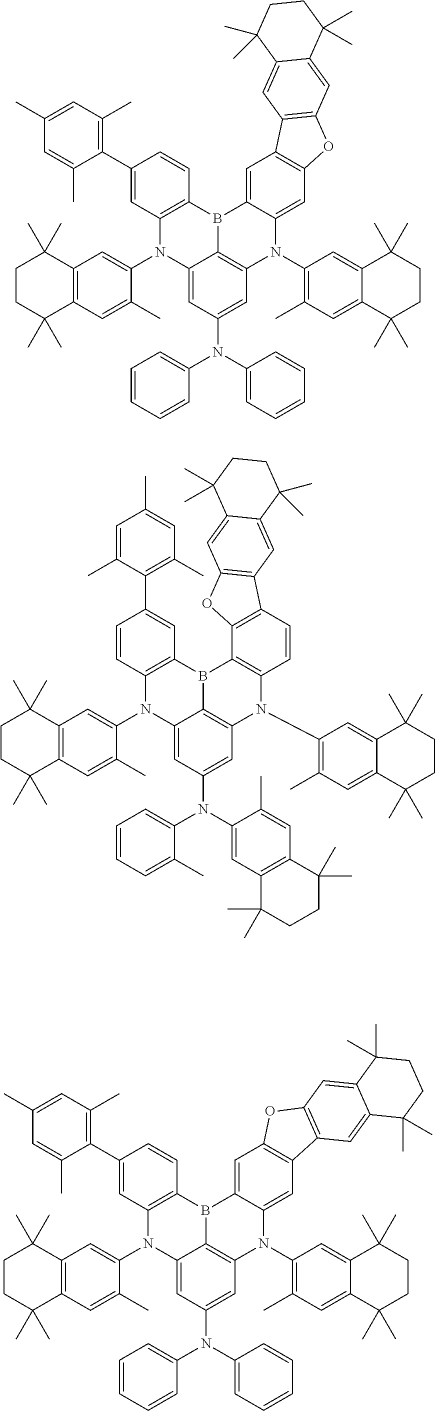

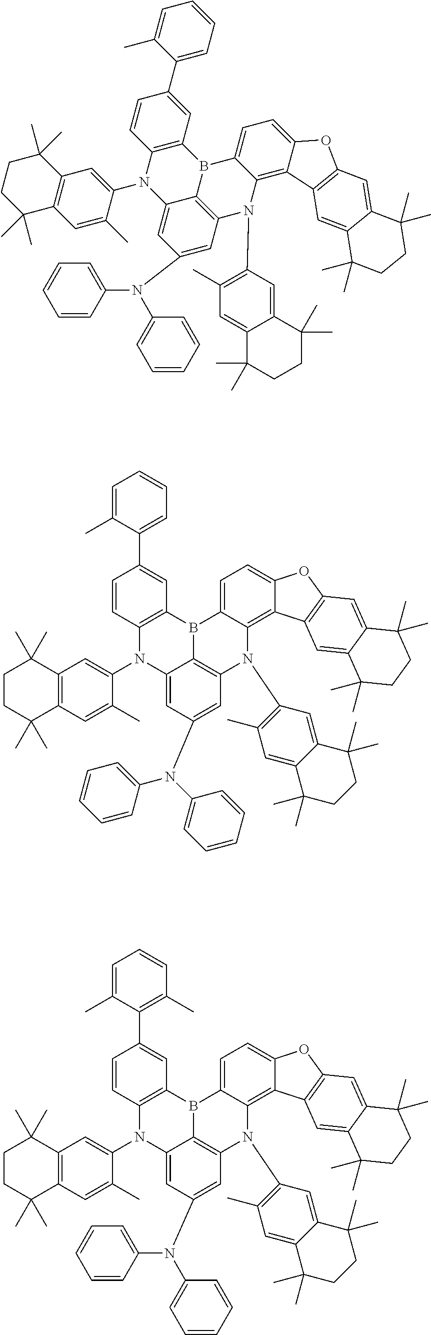

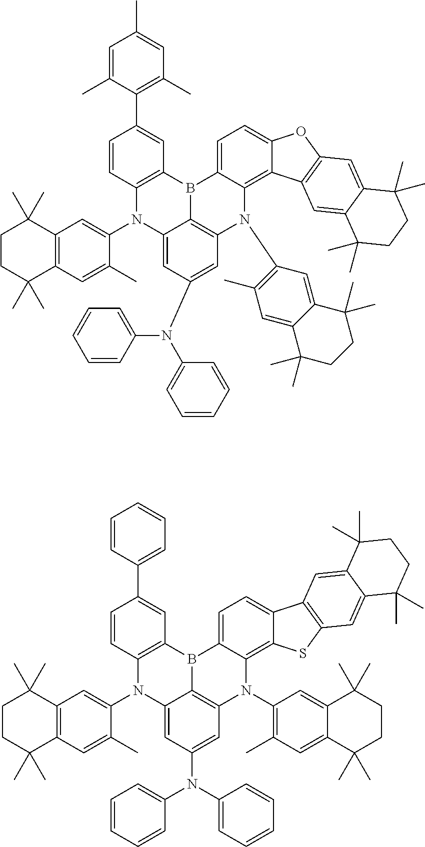

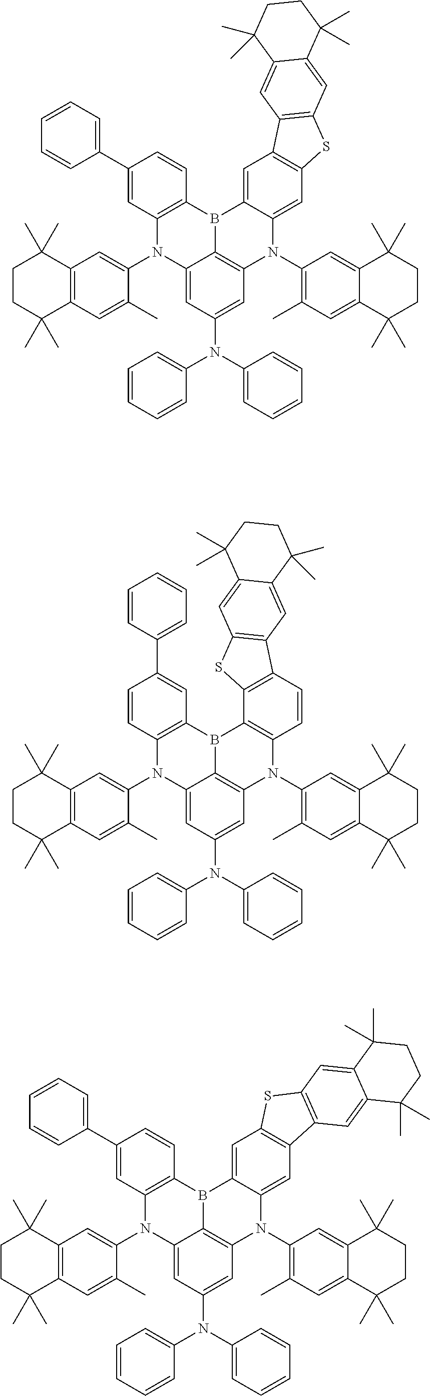

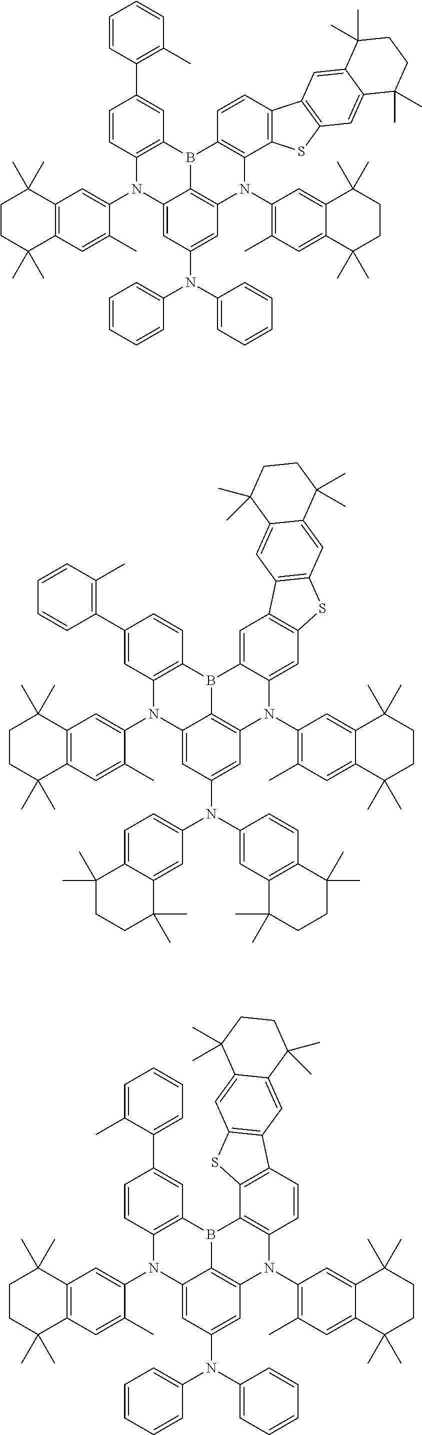

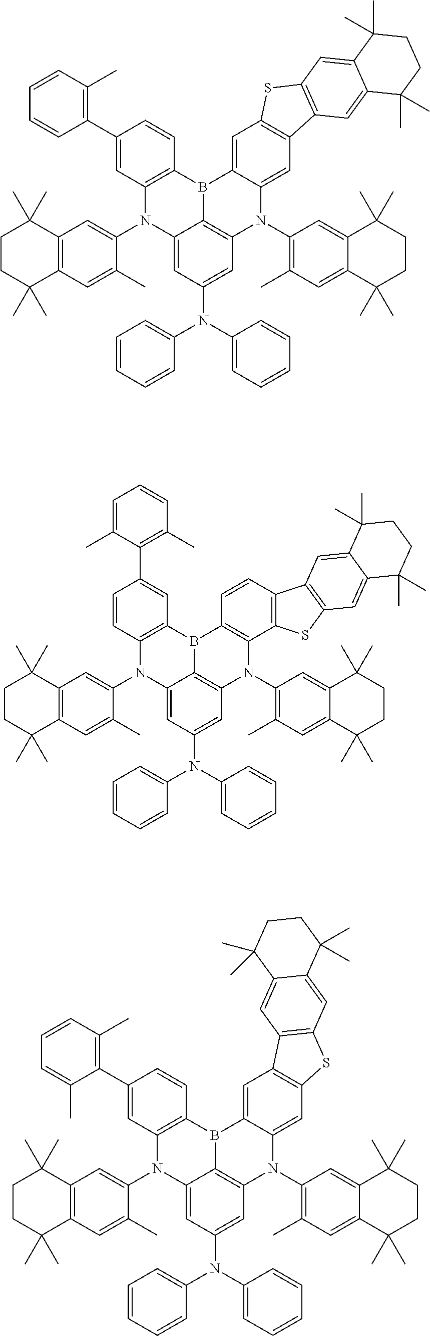

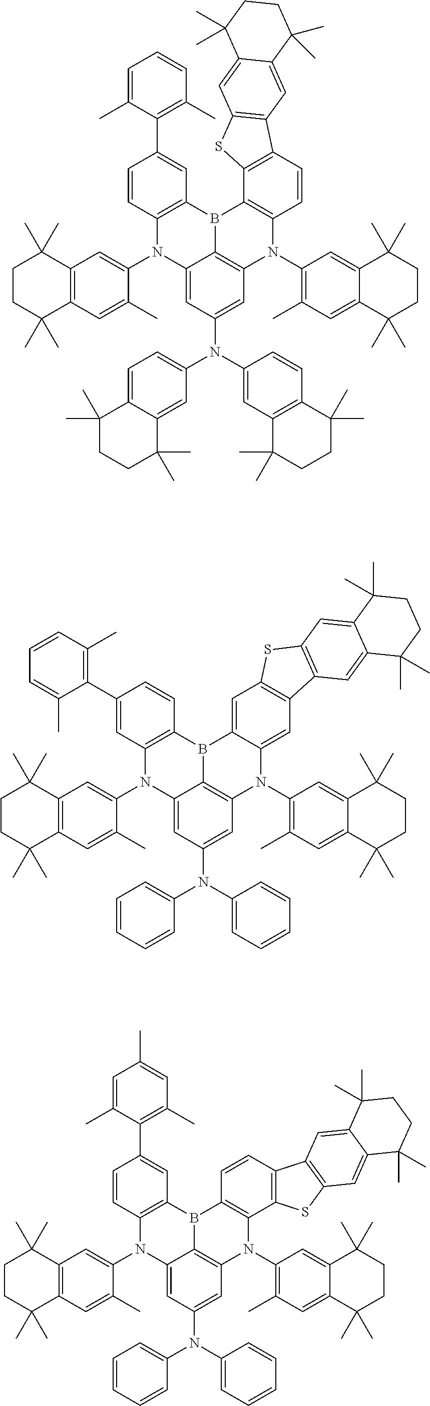

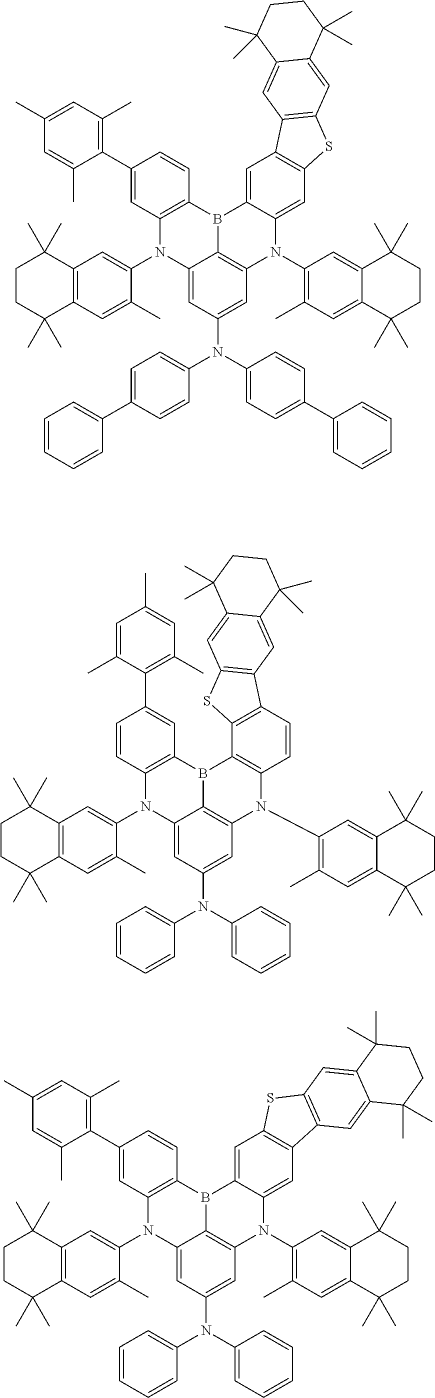

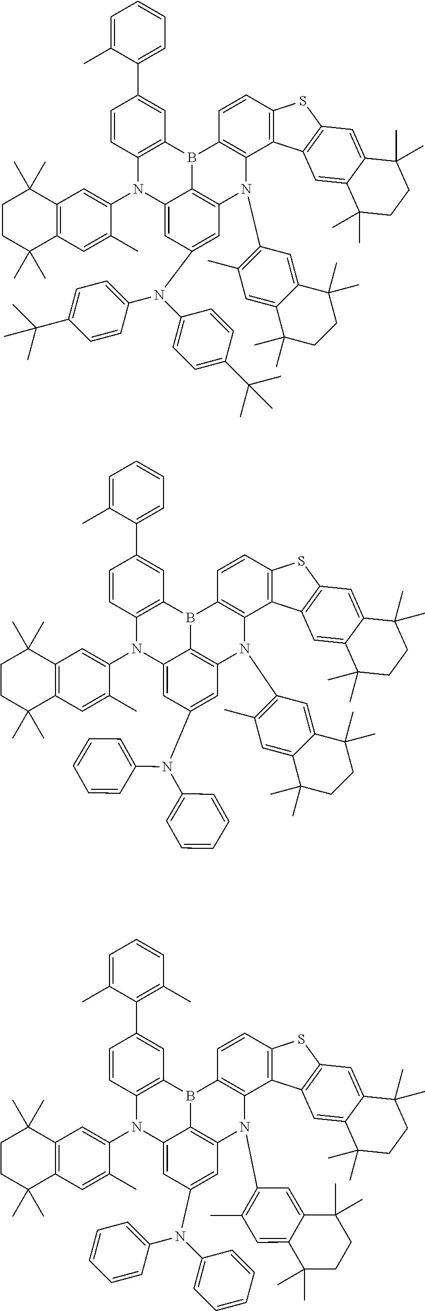

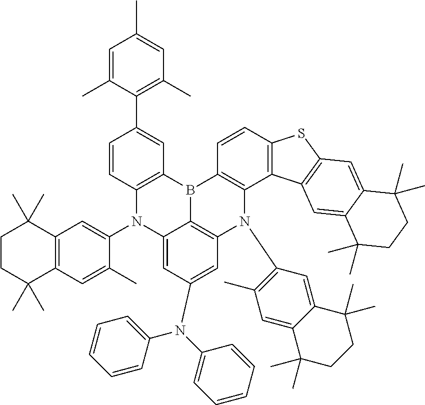

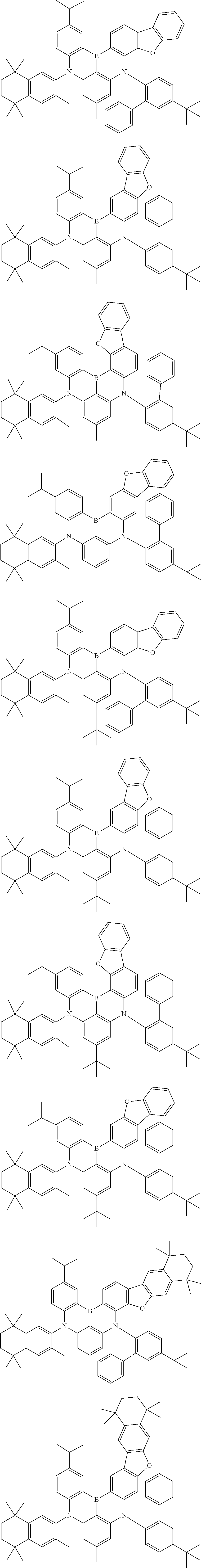

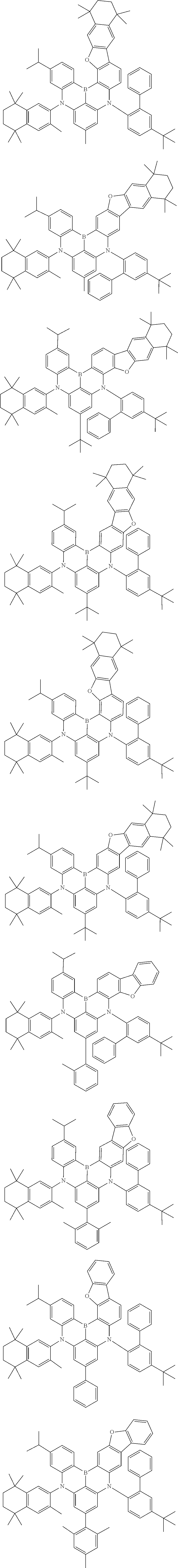

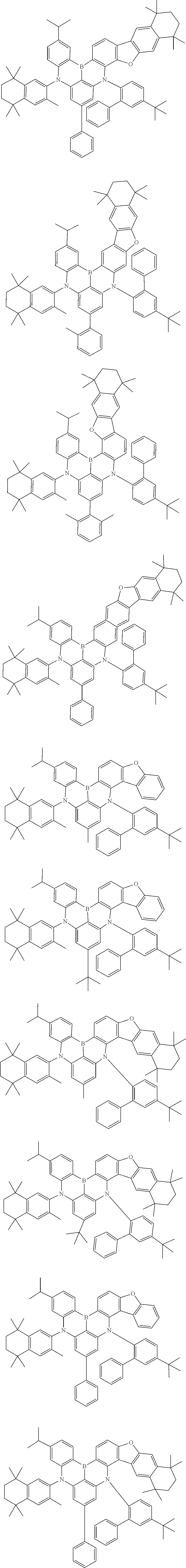

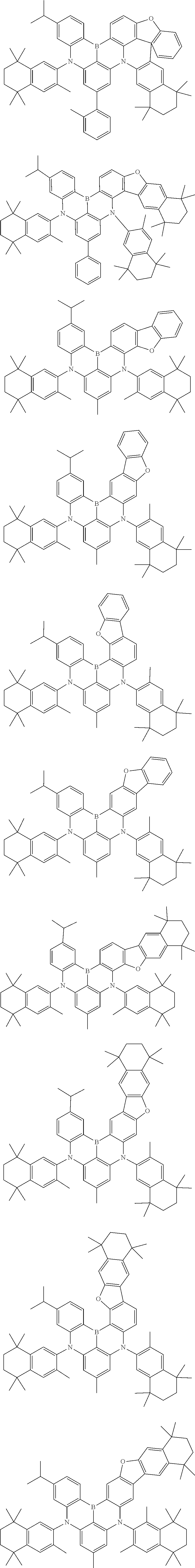

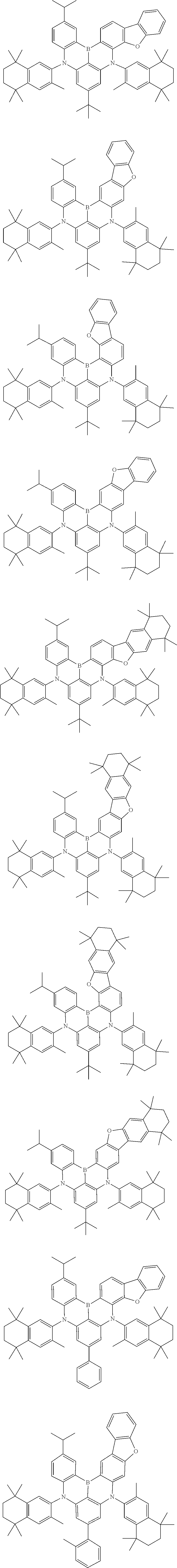

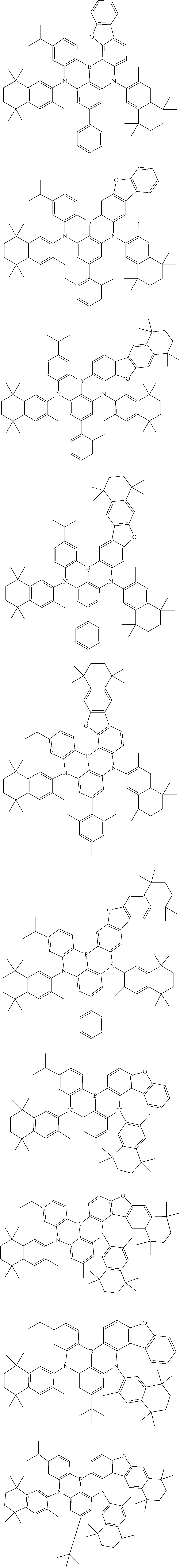

The substituents of the compound of Chemical Formula 1 can bond using methods known in the art, and types, positions and the number of the substituents can vary depending on technologies known in the art. For example, the compound can be synthesized using methods such as synthesis examples to describe later.

A conjugation length of the compound and the energy band gap are closely related. Specifically, the energy band gap decreases as the conjugation length of the compound increases.

In the present disclosure, compounds having various energy band gaps can be synthesized by introducing various substituents to the core structure as above. In addition, HOMO and LUMO energy levels of the compound can also be adjusted in the present disclosure by introducing various substituents to the core structure having a structure as above.

In addition, by introducing various substituents to the core structure having a structure as above, compounds having unique properties of the introduced substituents can be synthesized. For example, by introducing substituents normally used as hole injection layer materials, hole transfer layer materials, light emitting layer materials and electron transfer layer materials used when manufacturing an organic light emitting device to the core structure, materials satisfying conditions required for each organic material layer can be synthesized.

In addition, an organic light emitting device according to the present disclosure includes a first electrode; a second electrode provided opposite to the first electrode; and one or more organic material layers provided between the first electrode and the second electrode, wherein one or more layers of the organic material layers include the polycyclic compound described above.

The organic light emitting device of the present disclosure can be manufactured using common organic light emitting device manufacturing methods and materials except that one or more organic material layers are formed using the compound described above.

The compound can be formed to an organic material layer using a solution coating method as well as a vacuum deposition method when manufacturing the organic light emitting device. Herein, the solution coating method means spin coating, dip coating, inkjet printing, screen printing, a spray method, roll coating and the like, but is not limited thereto.

The organic material layer of the organic light emitting device of the present disclosure can be formed in a single layer structure, but can be formed in a multilayer structure in which two or more organic material layers are laminated. For example, the organic light emitting device of the present disclosure can have a structure including a hole injection layer, a hole transfer layer, a layer carrying out hole injection and hole transfer at the same time, a light emitting layer, an electron transfer layer, an electron injection layer and the like as the organic material layer. However, the structure of the organic light emitting device is not limited thereto, and can include a smaller number of organic material layers or a larger number of organic material layers.

In the organic light emitting device of the present disclosure, the organic material layer can include one or more of a hole blocking layer, an electron transfer layer, an electron injection layer, and a layer carrying out electron injection and electron transfer at the same time, and one or more layers of the above-described layers can include the polycyclic compound of Chemical Formula 1.

In the organic light emitting device of the present disclosure, the organic material layer can include one or more of a hole injection layer, a hole transfer layer, an electron blocking layer, and a layer carrying out hole injection and hole transfer at the same time, and one or more layers of the above-described layers can include the polycyclic compound of Chemical Formula 1.

In another embodiment, the organic material layer includes a light emitting layer, and the light emitting layer includes the polycyclic compound of Chemical Formula 1. As one example, the polycyclic compound of Chemical Formula 1 can be included as a dopant of the light emitting layer.

The light emitting layer including the polycyclic compound of Chemical Formula 1 has a maximum emission peak at 380 nm to 500 nm. In other words, the light emitting layer is a blue light emitting layer.

As another example, the light emitting layer including the polycyclic compound of Chemical Formula 1 includes the polycyclic compound of Chemical Formula 1 as a dopant, and can include a fluorescent host or a phosphorescent host.

In another embodiment, the light emitting layer including the polycyclic compound of Chemical Formula 1 includes the polycyclic compound of Chemical Formula 1 as a dopant, includes a fluorescent host or a phosphorescent host, and can include other organic compounds, metals or metal compounds as a dopant.

As another example, the light emitting layer including the polycyclic compound of Chemical Formula 1 includes the polycyclic compound of Chemical Formula 1 as a dopant, includes a fluorescent host or a phosphorescent host, and an iridium (Ir)-based dopant can be used therewith.

According to one embodiment of the present specification, the organic material layer includes a light emitting layer, the light emitting layer includes the above-described polycyclic compound as a dopant of the light emitting layer, and includes a compound of the following Chemical Formula H as a host of the light emitting layer:

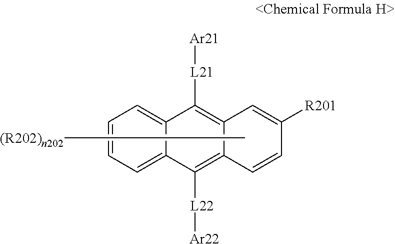

wherein in Chemical Formula H:

L21 and L22 are the same as or different from each other, and each independently is a direct bond, a substituted or unsubstituted arylene group, or a substituted or unsubstituted heteroarylene group;

Ar21 and Ar22 are the same as or different from each other, and each independently is a substituted or unsubstituted aryl group or a substituted or unsubstituted heterocyclic group;

R201 and R202 are the same as or different from each other, and each independently is hydrogen, deuterium, a halogen group, a substituted or unsubstituted alkyl group, a substituted or unsubstituted cycloalkyl group, a substituted or unsubstituted aryl group, or a substituted or unsubstituted heterocyclic group; and n202 is an integer of 0 to 7, and when n202 is 2 or greater, the R202s are the same as or different from each other.

In one embodiment of the present specification, L21 and L22 are the same as or different from each other, and each independently is a direct bond, a substituted or unsubstituted C6-C30 monocyclic or polycyclic arylene group, or a substituted or unsubstituted C2-C30 monocyclic or polycyclic heteroarylene group.

In one embodiment of the present specification, L21 and L22 are the same as or different from each other, and each independently is a direct bond, a substituted or unsubstituted C6-C20 monocyclic or polycyclic arylene group, or a substituted or unsubstituted C2-C20 monocyclic or polycyclic heteroarylene group.

In one embodiment of the present specification, L21 and L22 are the same as or different from each other, and each independently is a direct bond, a substituted or unsubstituted phenylene group, a substituted or unsubstituted biphenylene group, a substituted or unsubstituted naphthylene group, a substituted or unsubstituted divalent dibenzofuran group, or a substituted or unsubstituted divalent dibenzothiophene group.

In one embodiment of the present specification, L21 and L22 are the same as or different from each other, and each independently is a direct bond; a phenylene group that is unsubstituted or substituted with deuterium; a biphenylene group that is unsubstituted or substituted with deuterium; a naphthylene group that is unsubstituted or substituted with deuterium; a divalent dibenzofuran group that is unsubstituted or substituted with deuterium; or a divalent dibenzothiophene group that is unsubstituted or substituted with deuterium.

In one embodiment of the present specification, L21 and L22 are the same as or different from each other, and each independently is a direct bond; a phenylene group that is unsubstituted or substituted with deuterium; or a naphthylene group that is unsubstituted or substituted with deuterium.

In one embodiment of the present specification, one of L21 and L22 is a direct bond.

In one embodiment of the present specification, L21 is a direct bond.

In one embodiment of the present specification, L22 is a direct bond.

In one embodiment of the present specification, Ar21 and Ar22 are the same as or different from each other, and each independently is a substituted or unsubstituted monocyclic or polycyclic aryl group having 6 to 30 carbon atoms, or a substituted or unsubstituted monocyclic or polycyclic heterocyclic group having 2 to 30 carbon atoms.

In one embodiment of the present specification, Ar21 and Ar22 are the same as or different from each other, and each independently is a substituted or unsubstituted monocyclic or polycyclic aryl group having 6 to 20 carbon atoms, or a substituted or unsubstituted monocyclic or polycyclic heterocyclic group having 2 to 20 carbon atoms.

In one embodiment of the present specification, Ar21 and Ar22 are the same as or different from each other, and each independently is a substituted or unsubstituted monocyclic to tetracyclic aryl group having 6 to 20 carbon atoms, or a substituted or unsubstituted monocyclic to tetracyclic heterocyclic group having 6 to 20 carbon atoms.

In one embodiment of the present specification, Ar21 and Ar22 are the same as or different from each other, and each independently is a substituted or unsubstituted phenyl group, a substituted or unsubstituted biphenyl group, a substituted or unsubstituted terphenyl group, a substituted or unsubstituted naphthyl group, a substituted or unsubstituted anthracene group, a substituted or unsubstituted phenanthrene group; a substituted or unsubstituted phenalene group, a substituted or unsubstituted fluorene group, a substituted or unsubstituted benzofluorene group, a substituted or unsubstituted furan group, a substituted or unsubstituted thiophene group, a substituted or unsubstituted dibenzofuran group, a substituted or unsubstituted naphthobenzofuran group, a substituted or unsubstituted dibenzothiophene group, or a substituted or unsubstituted naphthobenzothiophene group.

In one embodiment of the present specification, Ar21 and Ar22 are the same as or different from each other, and each independently is a phenyl group that is unsubstituted or substituted with deuterium or a C6-C20 monocyclic or polycyclic aryl group; a biphenyl group that is unsubstituted or substituted with deuterium or a C6-C20 monocyclic or polycyclic aryl group; a naphthyl group that is unsubstituted or substituted with a C6-C20 monocyclic or polycyclic aryl group; a dibenzofuran group that is unsubstituted or substituted with deuterium or a C6-C20 monocyclic or polycyclic aryl group; a naphthobenzofuran group that is unsubstituted or substituted with deuterium or a C6-C20 monocyclic or polycyclic aryl group; a dibenzothiophene group that is unsubstituted or substituted with deuterium or a C6-C20 monocyclic or polycyclic aryl group; or a naphthobenzothiophene group that is unsubstituted or substituted with deuterium or a C6-C20 monocyclic or polycyclic aryl group.

In one embodiment of the present specification, Ar21 and Ar22 are the same as or different from each other, and each independently is a phenyl group that is unsubstituted or substituted with deuterium; a biphenyl group that is unsubstituted or substituted with deuterium; a terphenyl group; a naphthyl group that is unsubstituted or substituted with deuterium; a phenanthrene group; a dibenzofuran group; a naphthobenzofuran group; a dibenzothiophene group; or a naphthobenzothiophene group.

In one embodiment of the present specification, any one of Ar21 and Ar22 is a substituted or unsubstituted aryl group, and the other one is a substituted or unsubstituted heterocyclic group.

In one embodiment of the present specification, Ar21 is a substituted or unsubstituted aryl group, and Ar22 is a substituted or unsubstituted heterocyclic group.

In one embodiment of the present specification, Ar21 is a substituted or unsubstituted heterocyclic group, and Ar22 is a substituted or unsubstituted aryl group.

In one embodiment of the present specification, R201 is hydrogen, deuterium, a halogen group, a substituted or unsubstituted C1-C10 linear or branched alkyl group, a substituted or unsubstituted C3-C30 monocyclic or polycyclic cycloalkyl group, a substituted or unsubstituted C6-C30 monocyclic or polycyclic aryl group, or a substituted or unsubstituted C2-C30 monocyclic or polycyclic heterocyclic group.

In one embodiment of the present specification, R201 is hydrogen, deuterium, fluorine, a substituted or unsubstituted C1-C10 linear or branched alkyl group, a substituted or unsubstituted C3-C10 monocyclic or polycyclic cycloalkyl group, a substituted or unsubstituted C6-C30 monocyclic or polycyclic aryl group, or a substituted or unsubstituted C2-C30 monocyclic or polycyclic heterocyclic group.

In one embodiment of the present specification, R201 is hydrogen, a substituted or unsubstituted C6-C30 monocyclic or polycyclic aryl group, or a substituted or unsubstituted C2-C30 monocyclic or polycyclic heterocyclic group.

In one embodiment of the present specification, R201 is hydrogen, a substituted or unsubstituted C6-C20 monocyclic or polycyclic aryl group, or a substituted or unsubstituted C2-C20 monocyclic or polycyclic heterocyclic group.

In one embodiment of the present specification, R201 is hydrogen; a substituted or unsubstituted C6-C20 monocyclic to tetracyclic aryl group, or a substituted or unsubstituted C6-C20 monocyclic to tetracyclic heterocyclic group.

In one embodiment of the present specification, R201 is hydrogen; a substituted or unsubstituted phenyl group, a substituted or unsubstituted biphenyl group, a substituted or unsubstituted terphenyl group, a substituted or unsubstituted naphthyl group, a substituted or unsubstituted anthracene group, a substituted or unsubstituted phenanthrene group, a substituted or unsubstituted phenalene group, a substituted or unsubstituted fluorene group, a substituted or unsubstituted benzofluorene group, a substituted or unsubstituted furan group, a substituted or unsubstituted thiophene group, a substituted or unsubstituted dibenzofuran group, a substituted or unsubstituted naphthobenzofuran group, a substituted or unsubstituted dibenzothiophene group, or a substituted or unsubstituted naphthobenzothiophene group.

In one embodiment of the present specification, R201 is hydrogen; deuterium; a phenyl group that is unsubstituted or substituted with deuterium or a C6-C20 monocyclic or polycyclic aryl group; a biphenyl group that is unsubstituted or substituted with a C6-C20 monocyclic or polycyclic aryl group; a naphthyl group that is unsubstituted or substituted with deuterium or a C6-C20 monocyclic or polycyclic aryl group; a dibenzofuran group that is unsubstituted or substituted with deuterium or a C6-C20 monocyclic or polycyclic aryl group; a naphthobenzofuran group that is unsubstituted or substituted with deuterium or a C6-C20 monocyclic or polycyclic aryl group; a dibenzothiophene group that is unsubstituted or substituted with deuterium or a C6-C20 monocyclic or polycyclic aryl group; or a naphthobenzothiophene group that is unsubstituted or substituted with deuterium or a C6-C20 monocyclic or polycyclic aryl group.

In one embodiment of the present specification, R201 is hydrogen; deuterium; a phenyl group that is unsubstituted or substituted with deuterium, a phenyl group or a naphthyl group; a biphenyl group; a naphthyl group that is unsubstituted or substituted with deuterium, a phenyl group or a naphthyl group; a dibenzofuran group; a naphthobenzofuran group; a dibenzothiophene group; or a naphthobenzothiophene group.

According to one embodiment of the present specification, R202 is hydrogen or deuterium.

According to one embodiment of the present specification, four or more of R202s are deuterium.

According to one embodiment of the present specification, R202 is hydrogen.

According to one embodiment of the present specification, R202 is deuterium.

In one embodiment of the present specification, when the compound of Chemical Formula H is substituted with deuterium, hydrogen at a substitutable position is substituted with deuterium by 30% or more. In another embodiment, hydrogen at a substitutable position is substituted with deuterium by 40% or more in the structure of Chemical Formula H. In another embodiment, hydrogen at a substitutable position is substituted with deuterium by 60% or more in the structure of Chemical Formula H.

In another embodiment, hydrogen at a substitutable position is substituted with deuterium by 80% or more in the structure of Chemical Formula H. In another embodiment, hydrogen at a substitutable position is substituted with deuterium by 100% in the structure of Chemical Formula H.

In one embodiment of the present specification, the compound of Chemical Formula H is any one compound selected from among the following compounds:

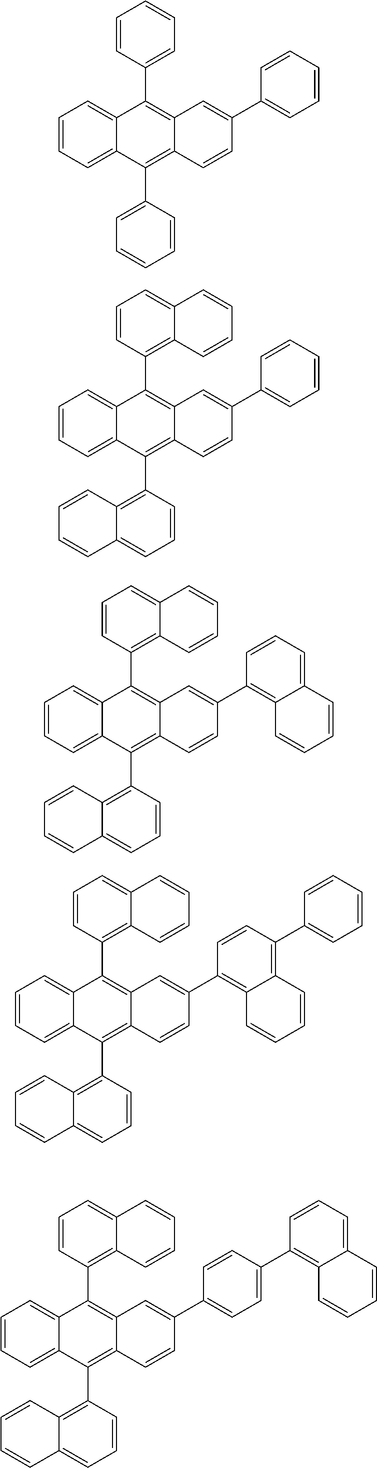

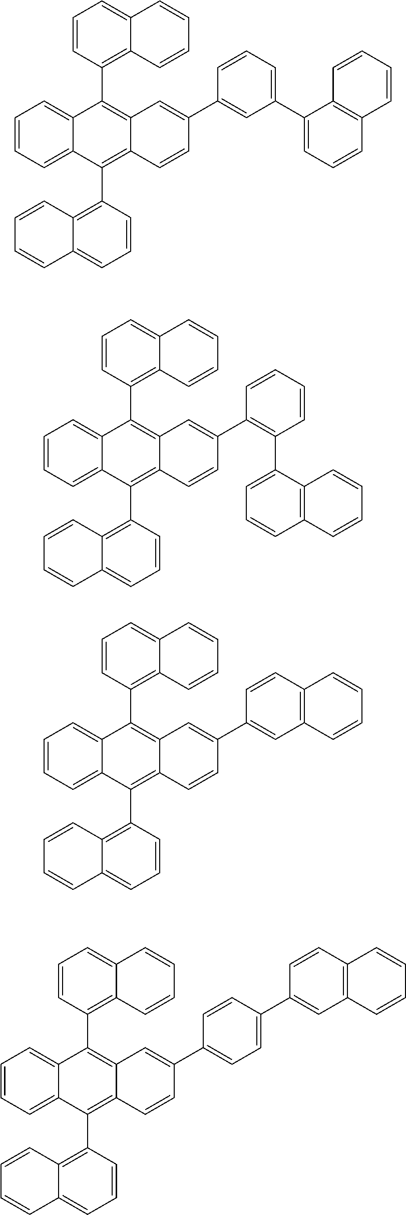

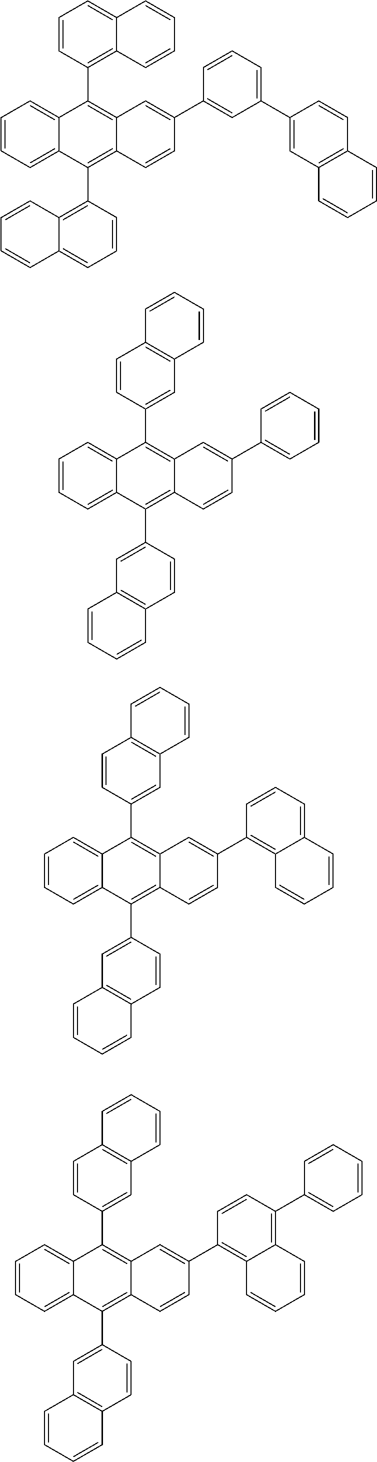

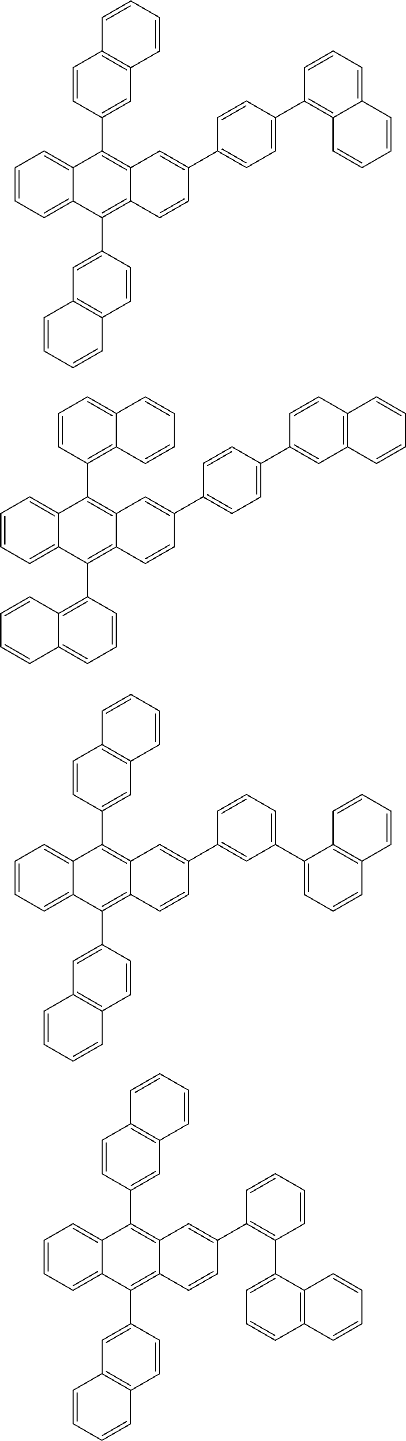

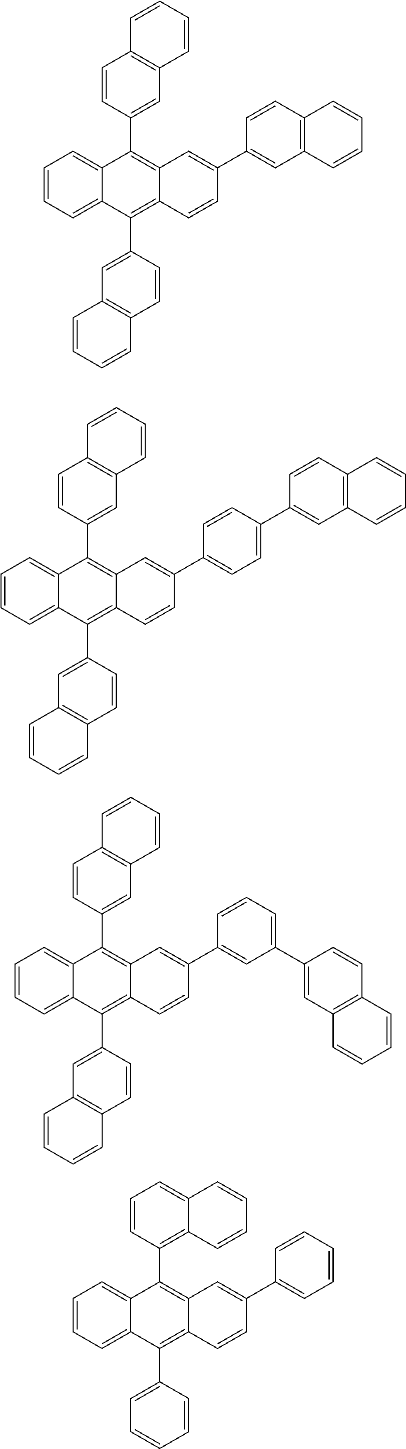

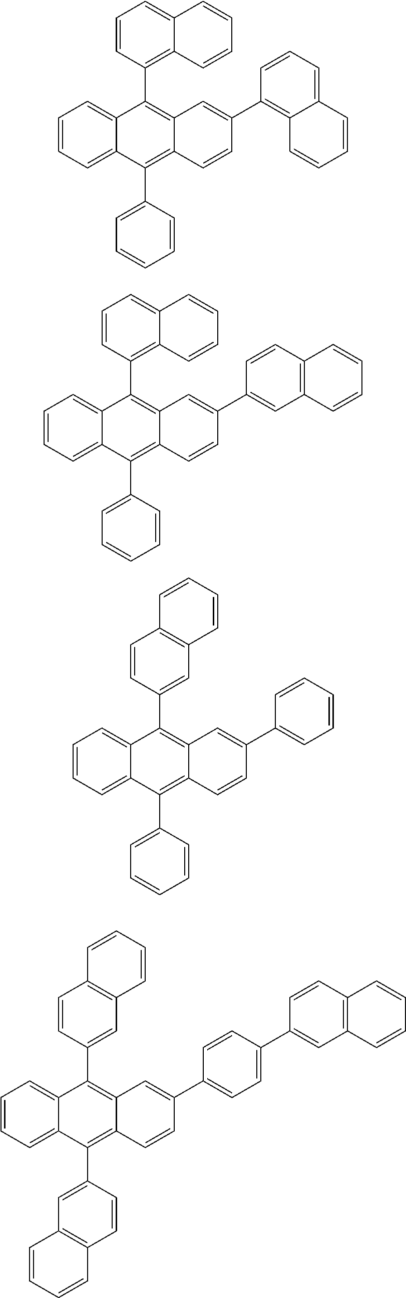

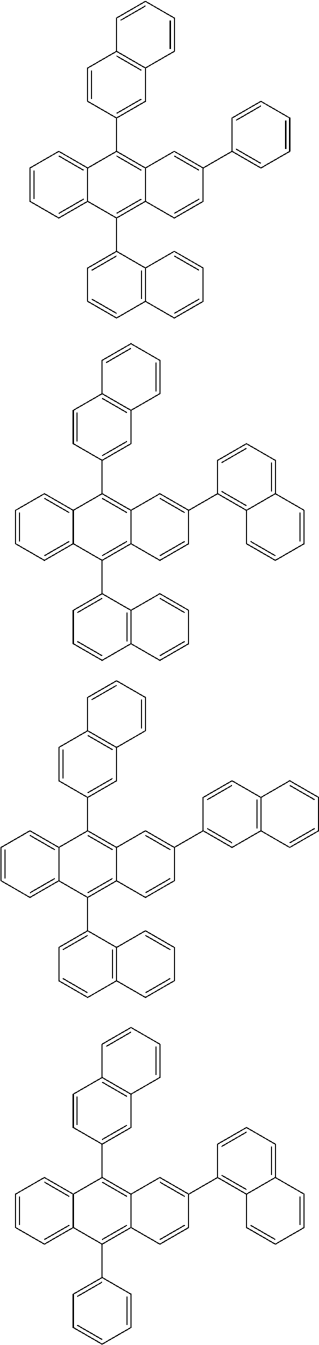

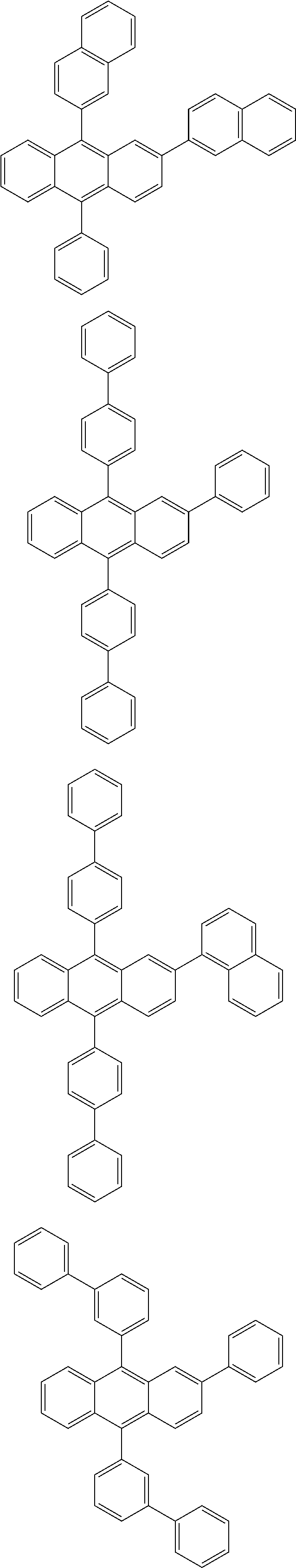

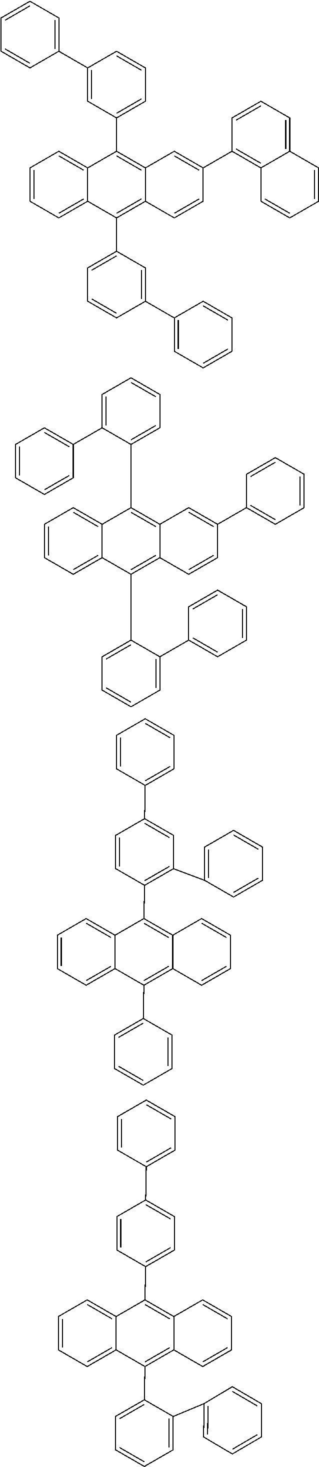

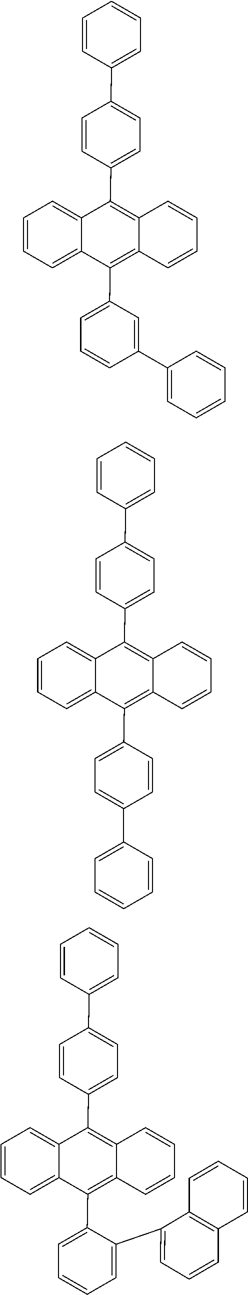

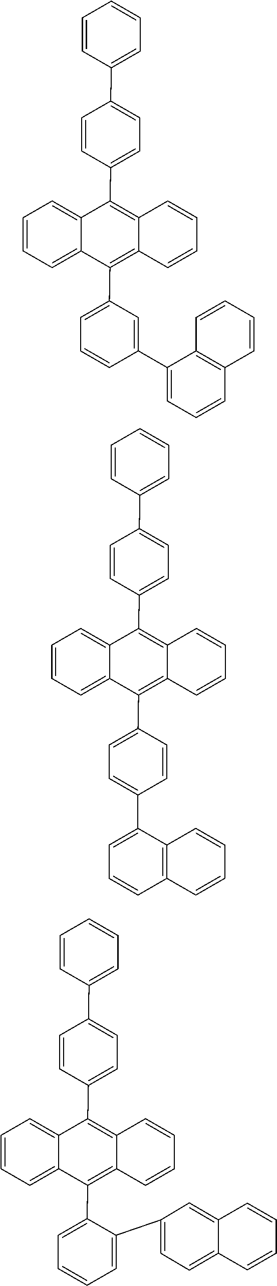

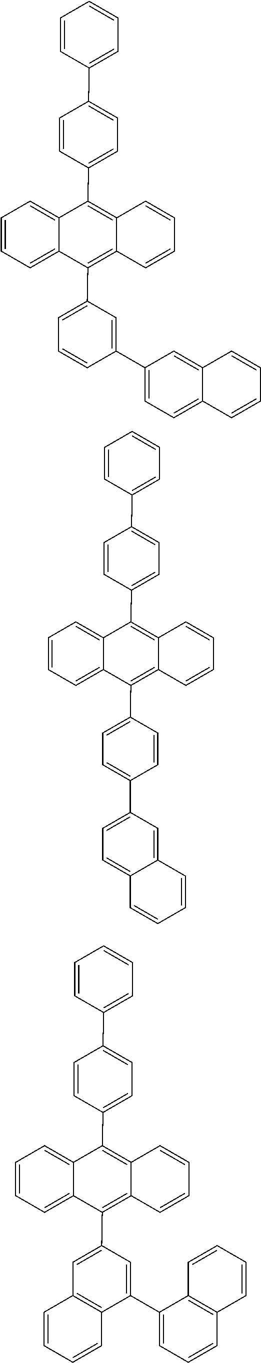

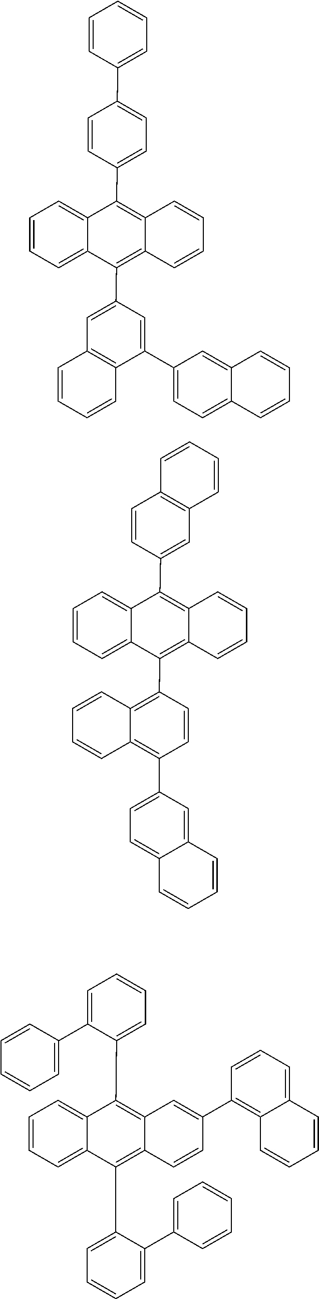

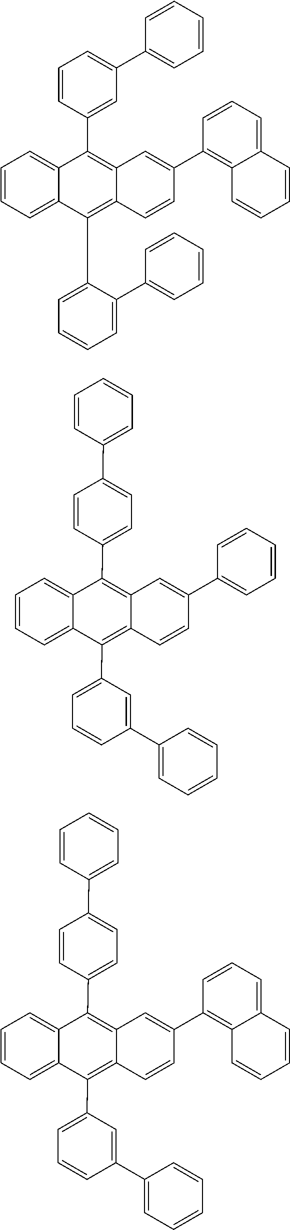

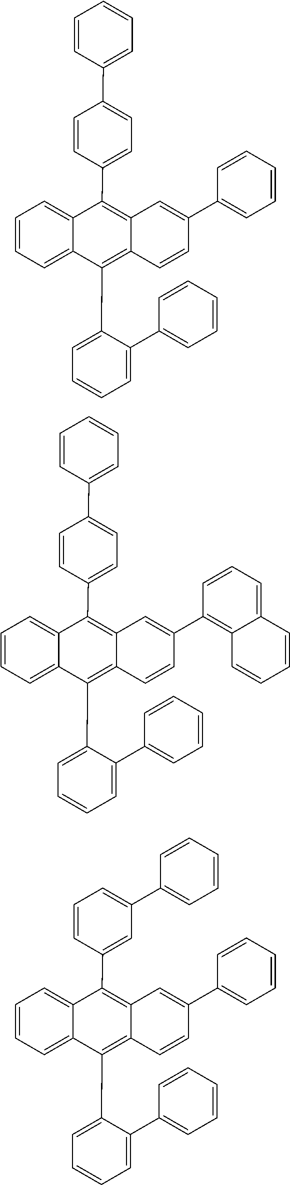

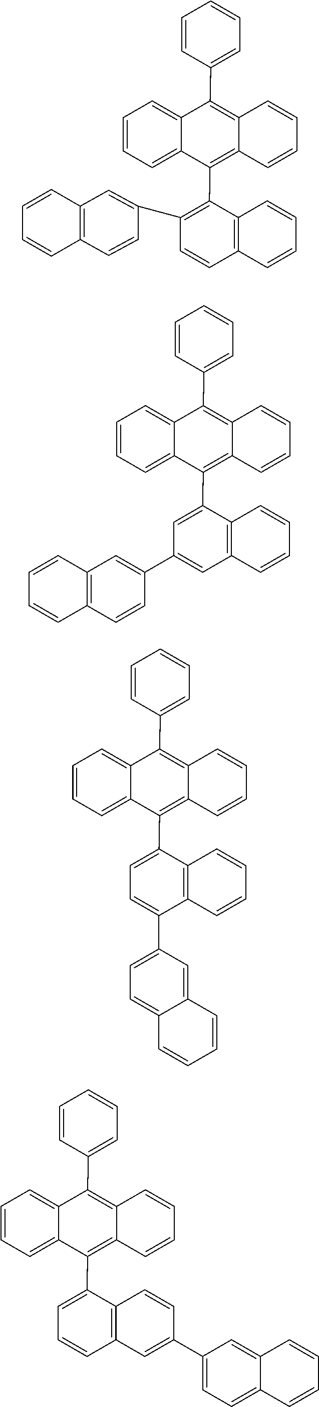

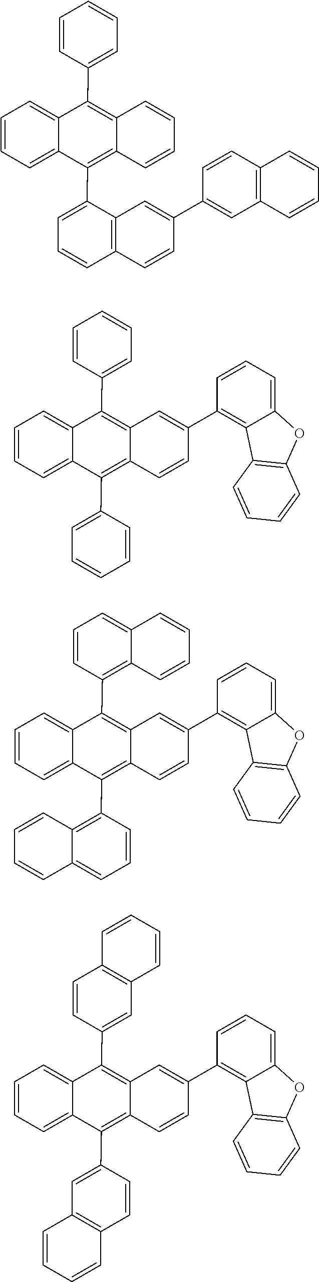

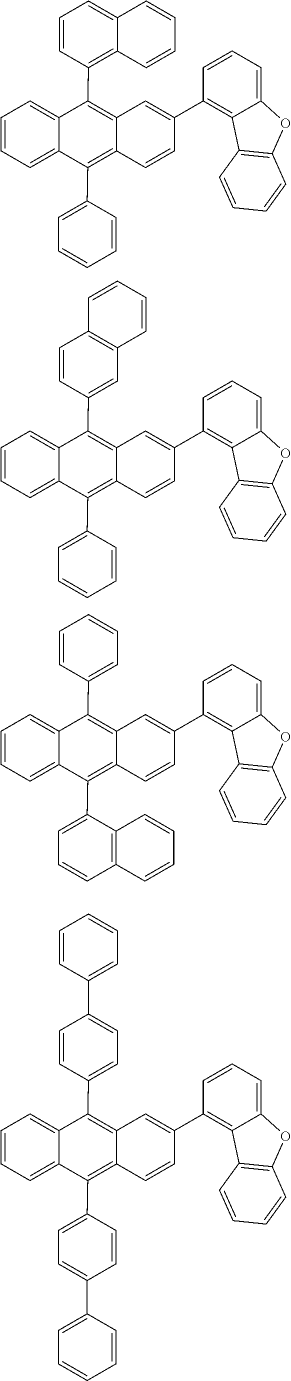

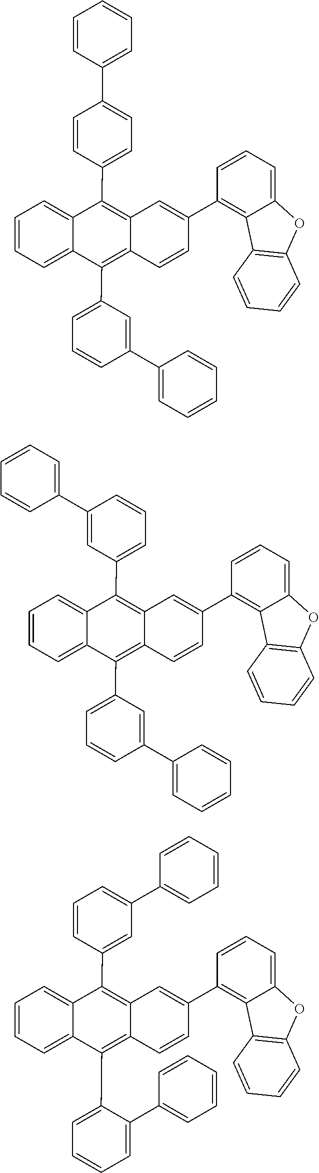

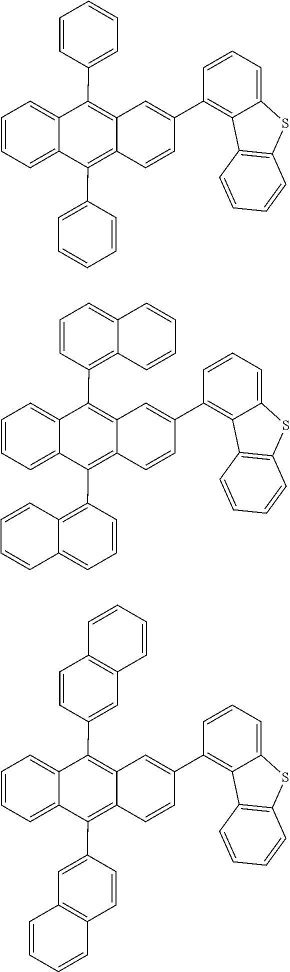

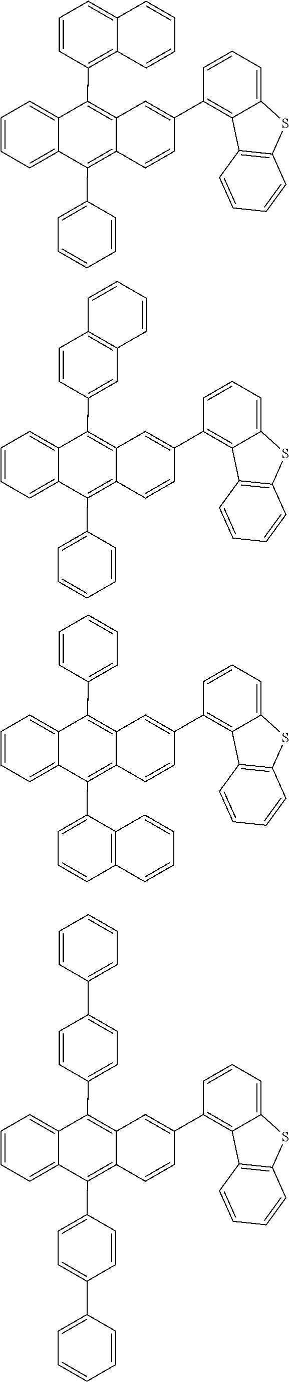

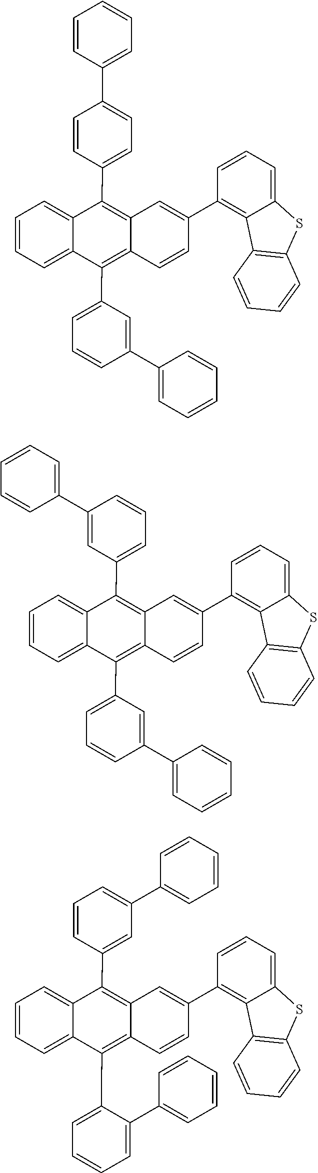

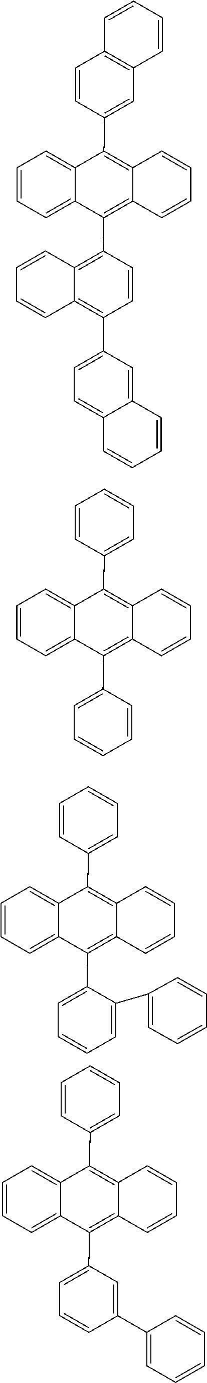

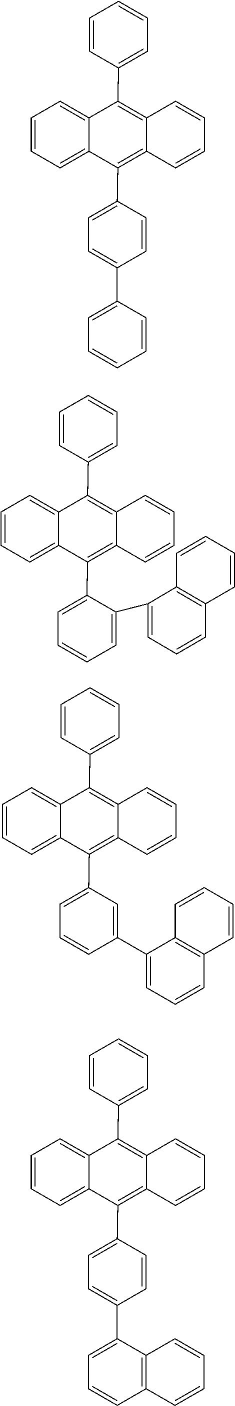

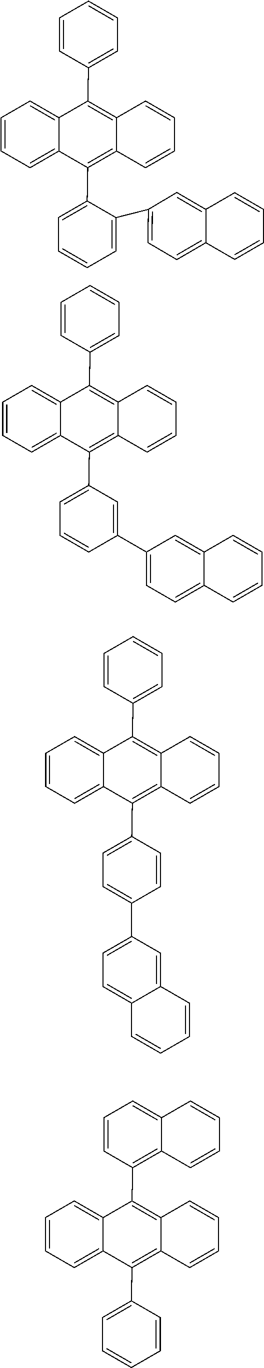

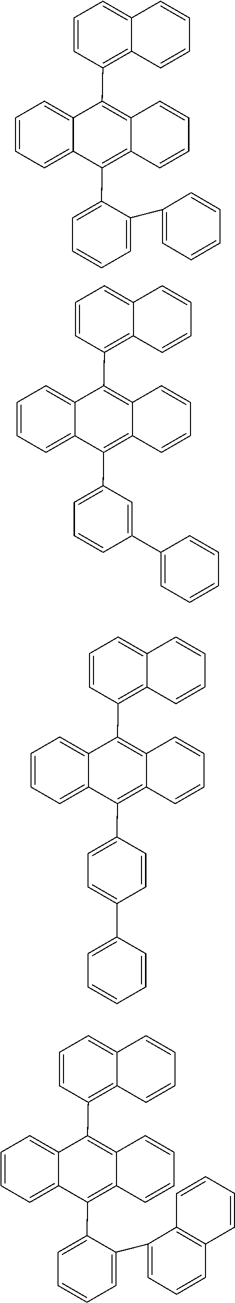

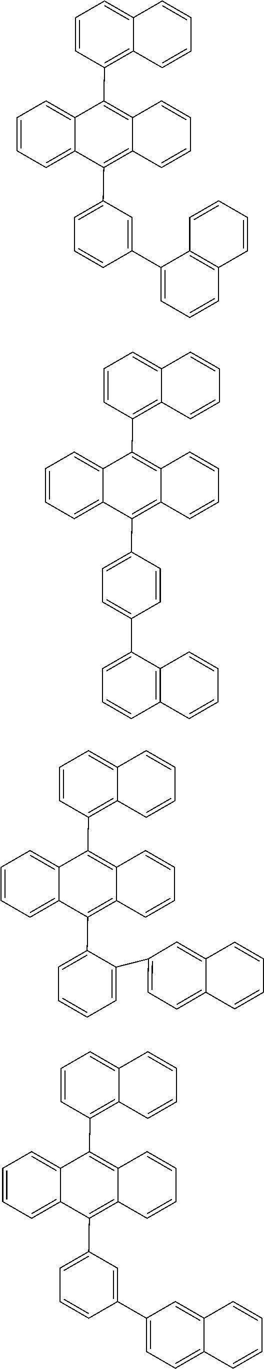

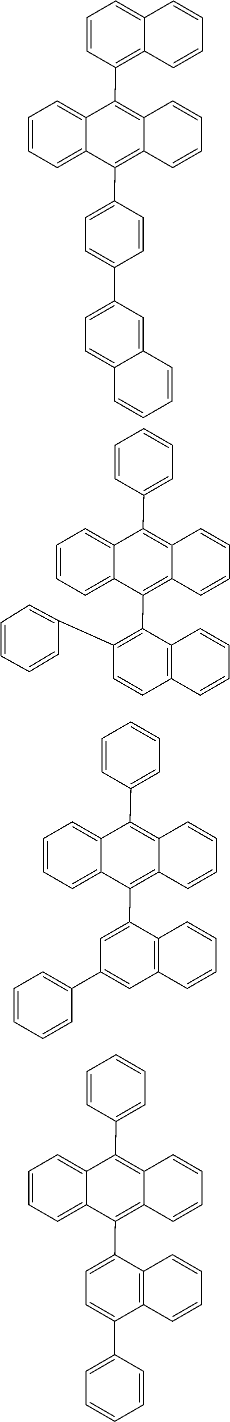

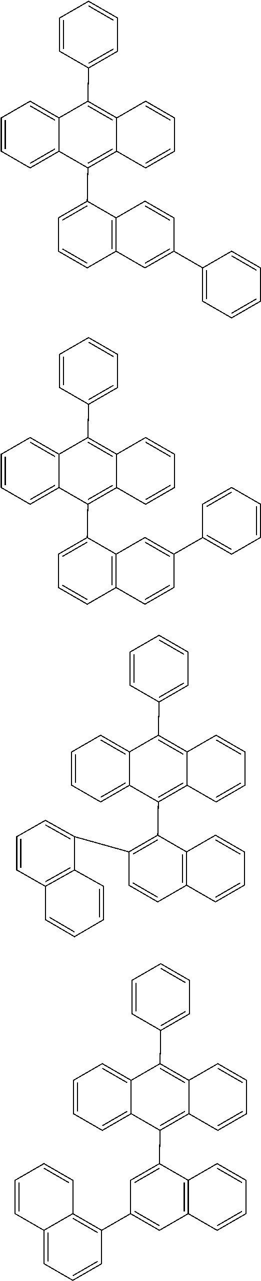

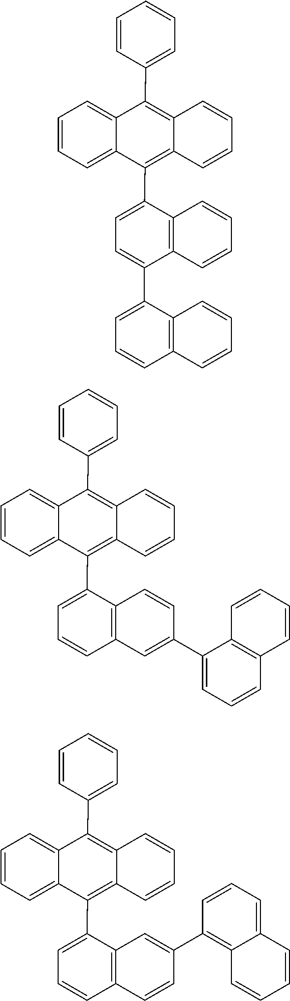

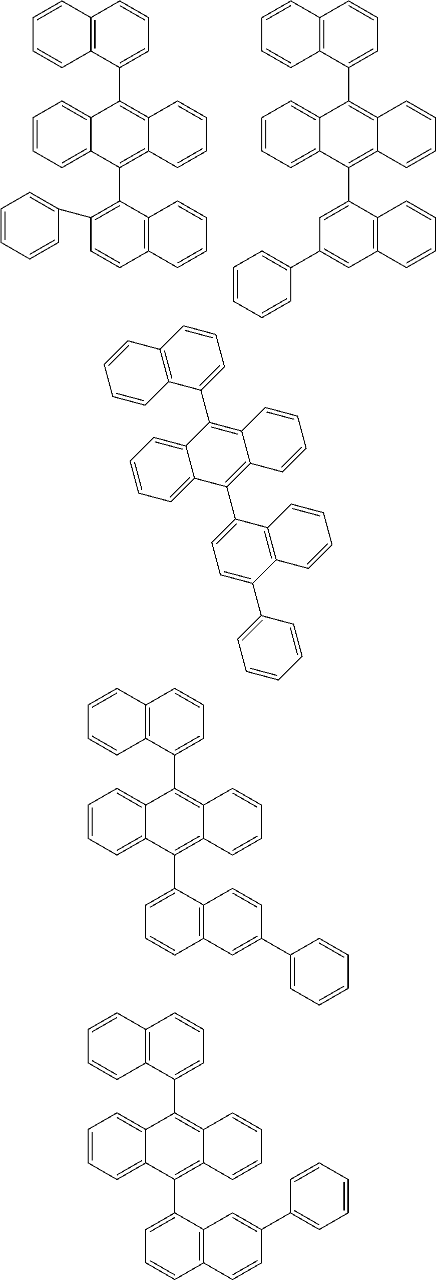

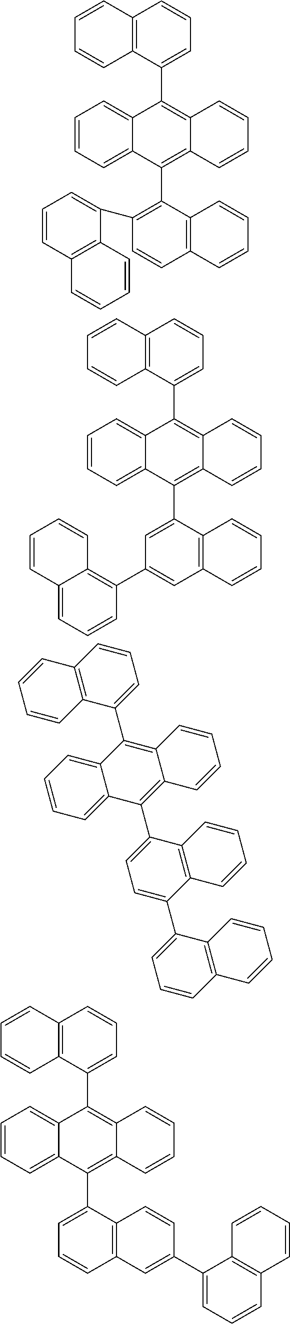

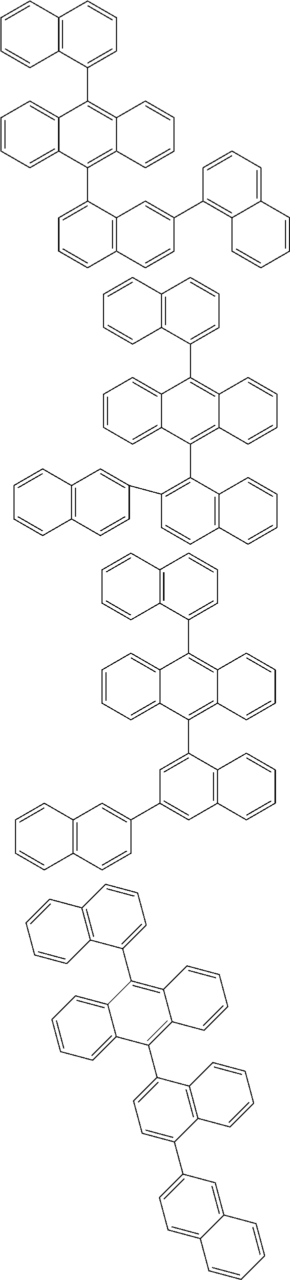

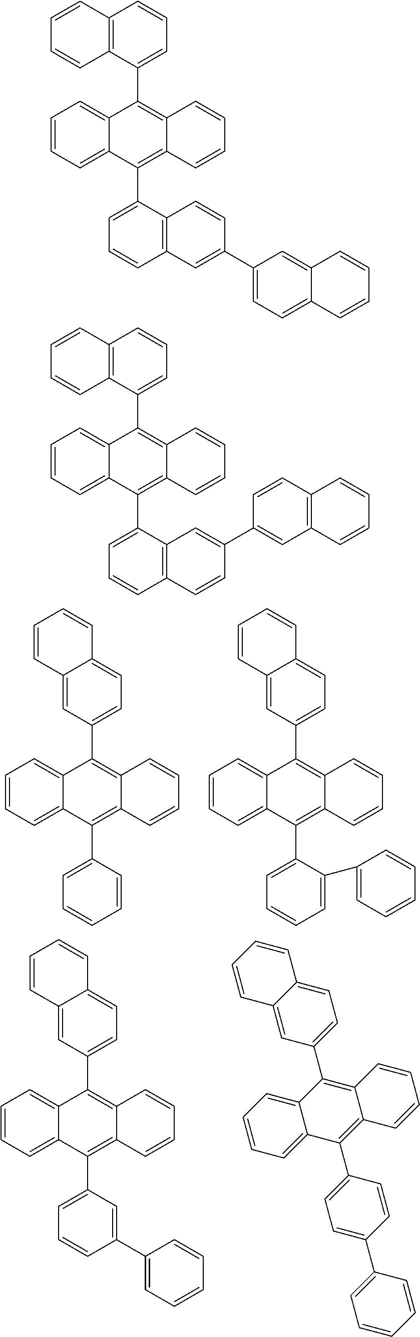

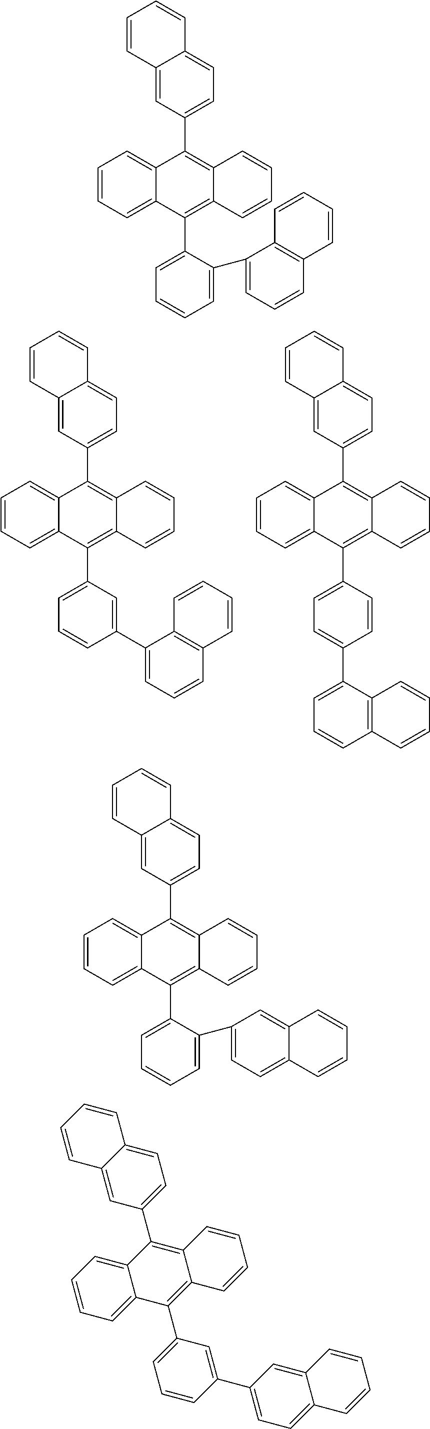

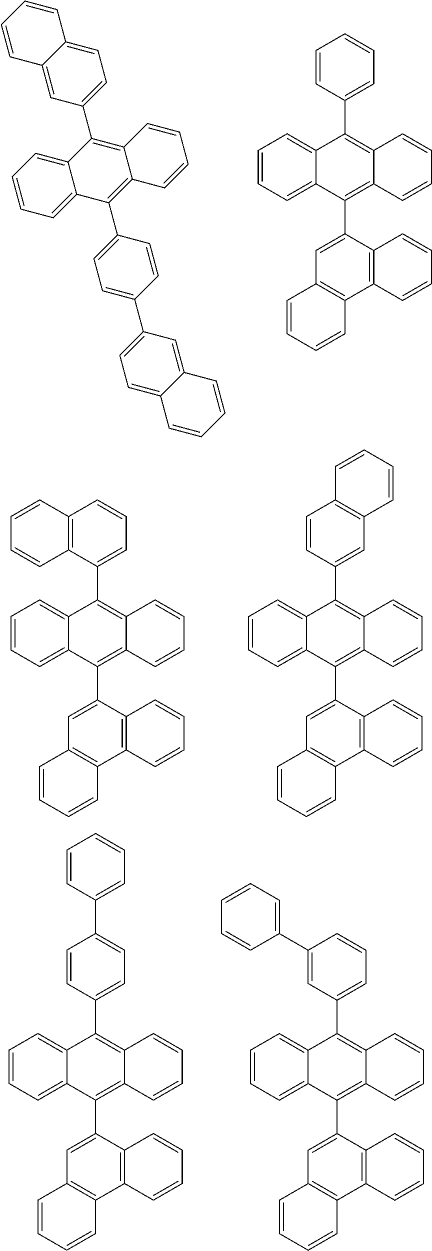

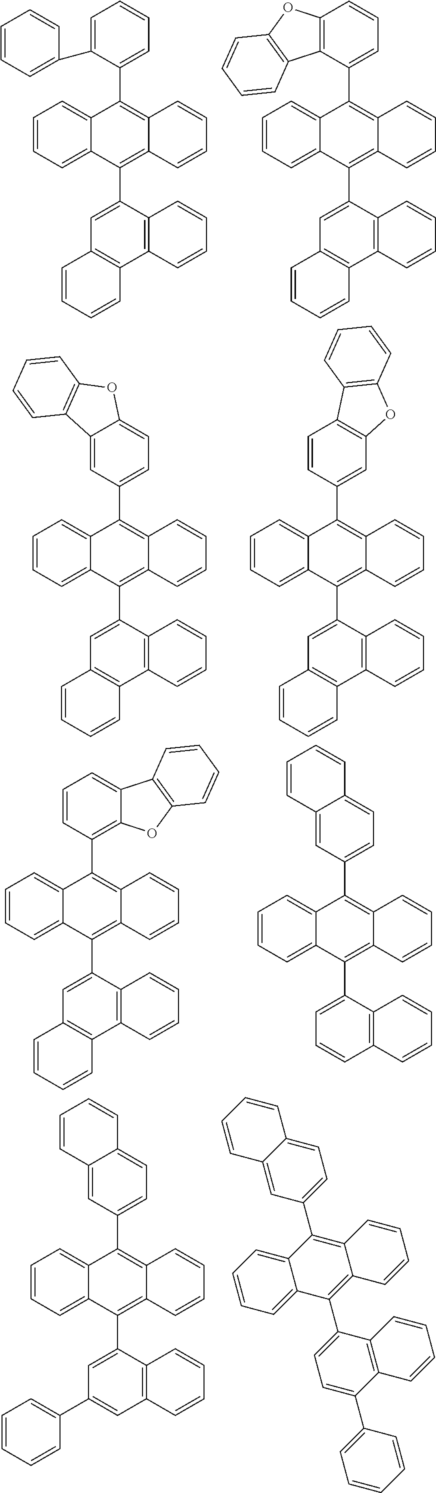

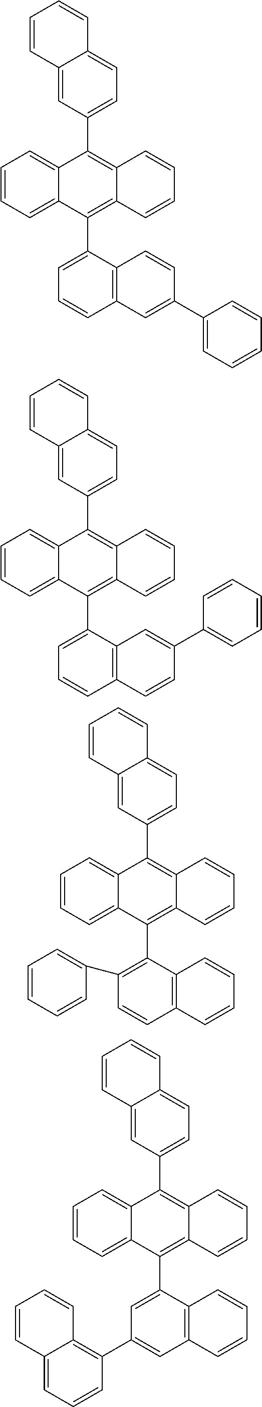

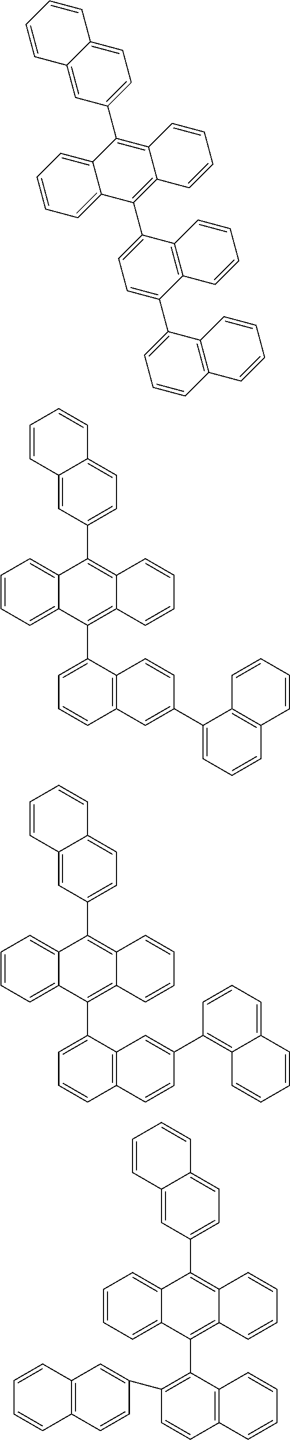

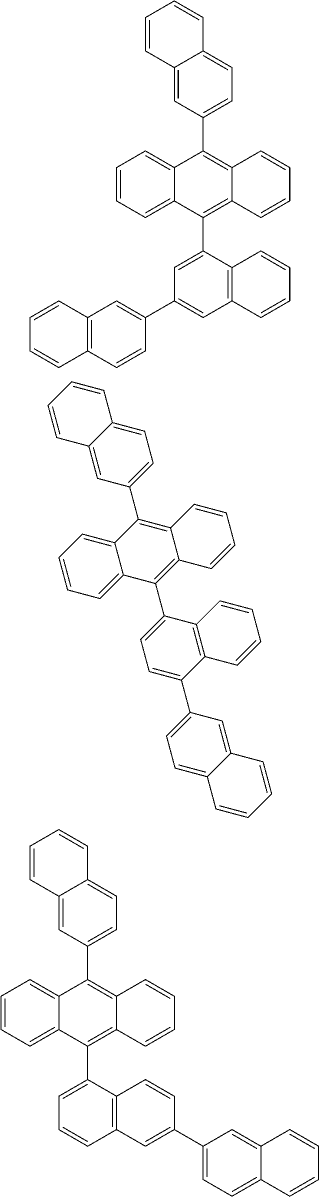

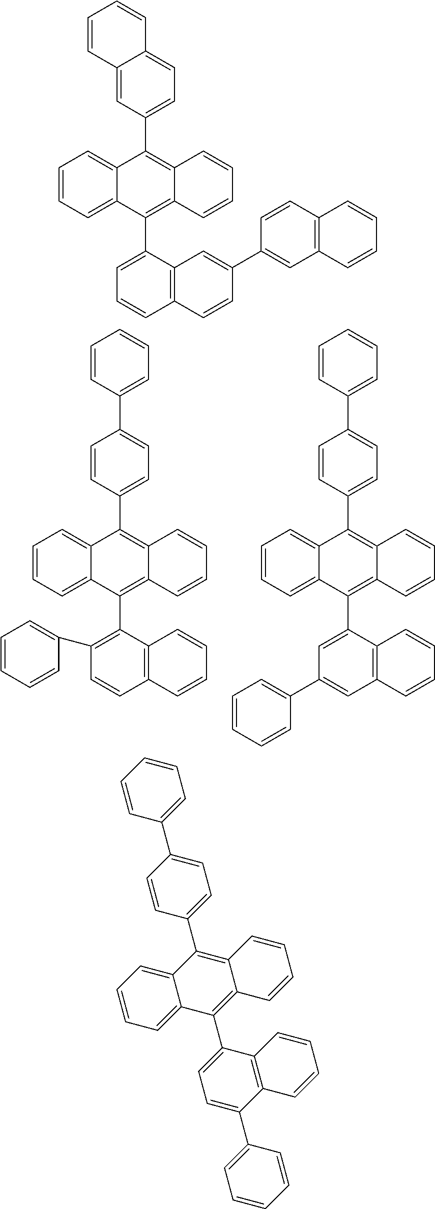

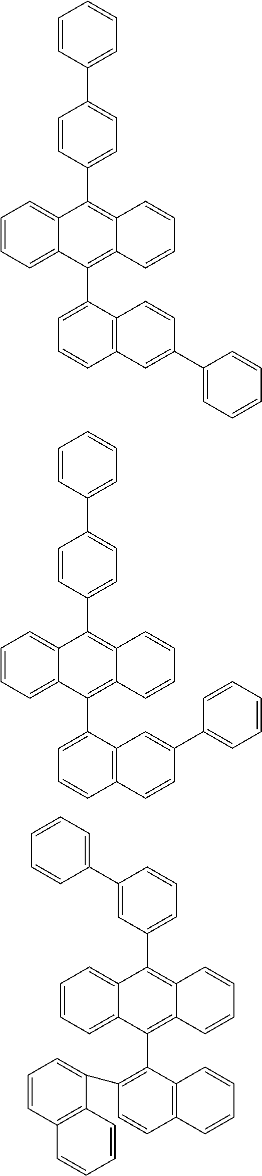

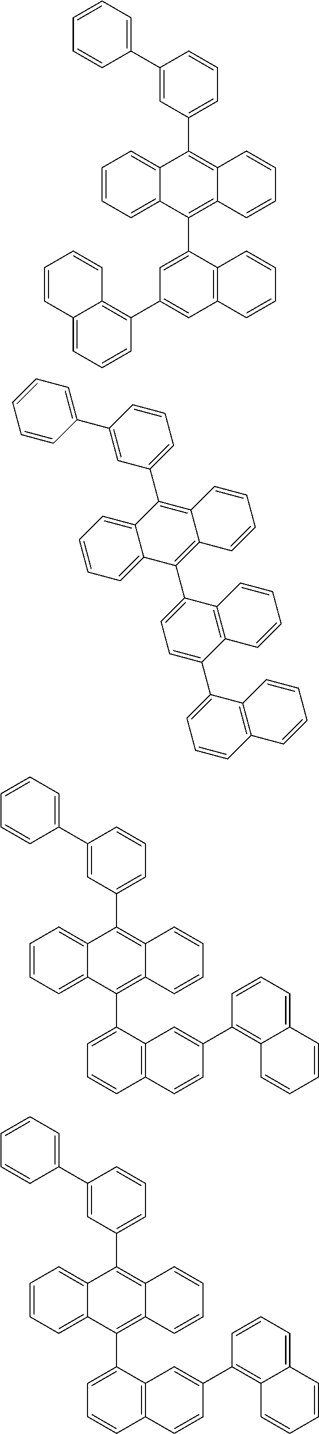

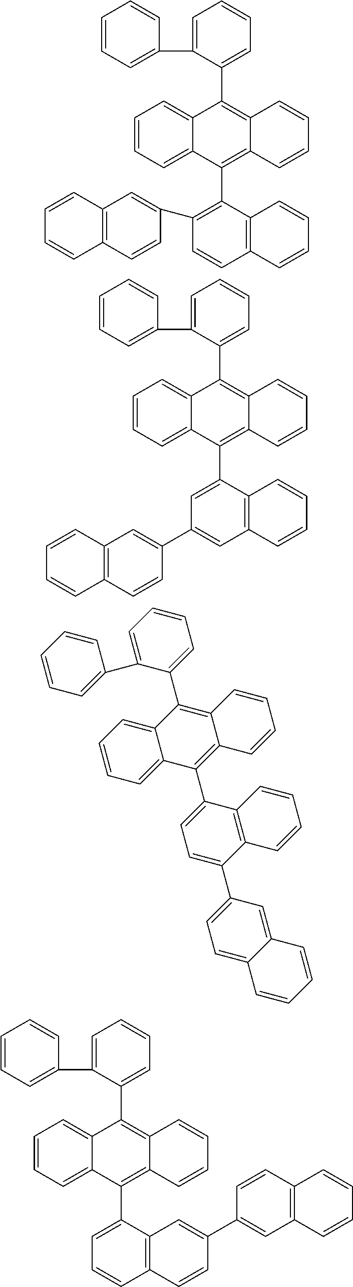

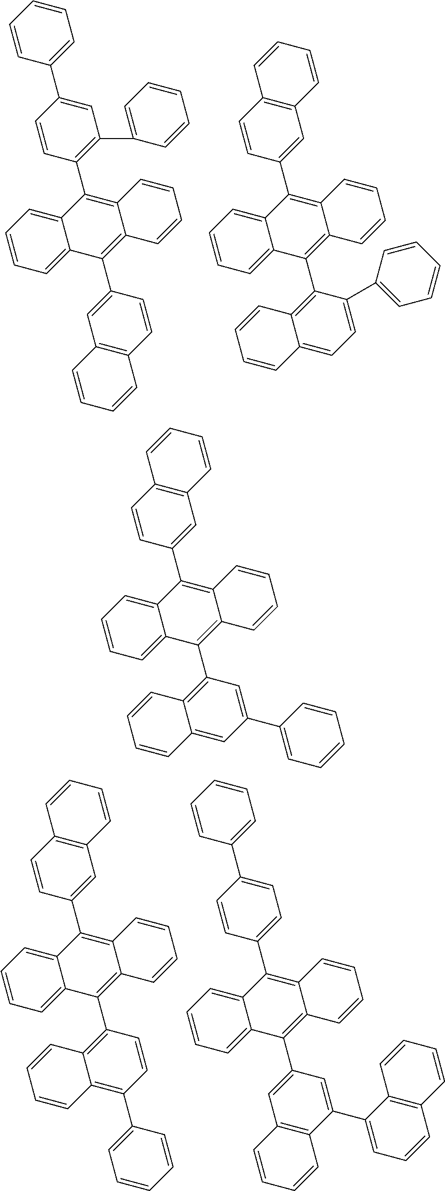

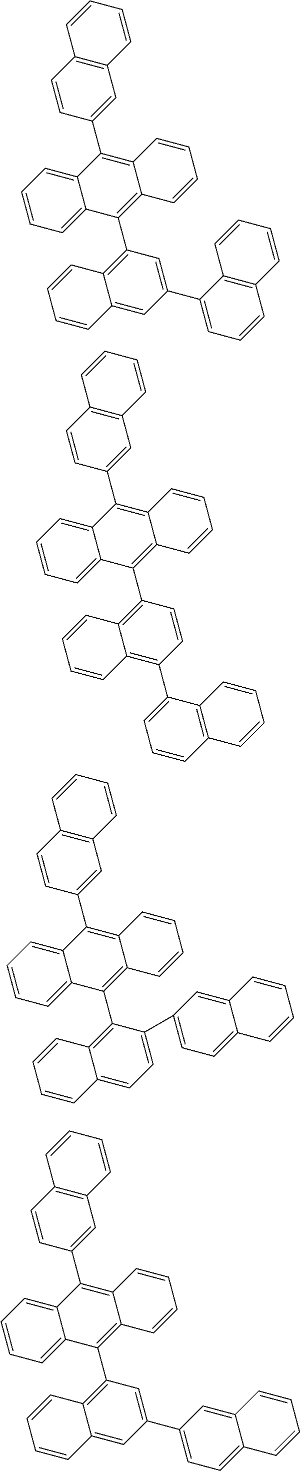

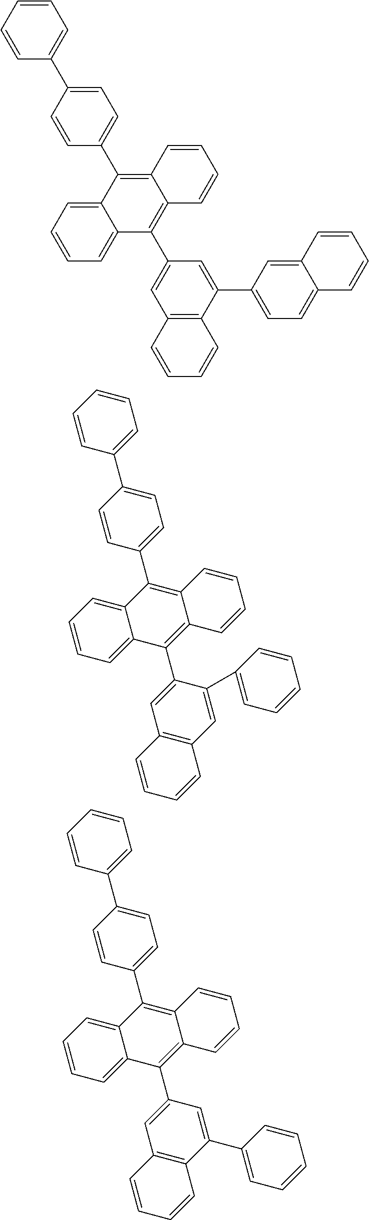

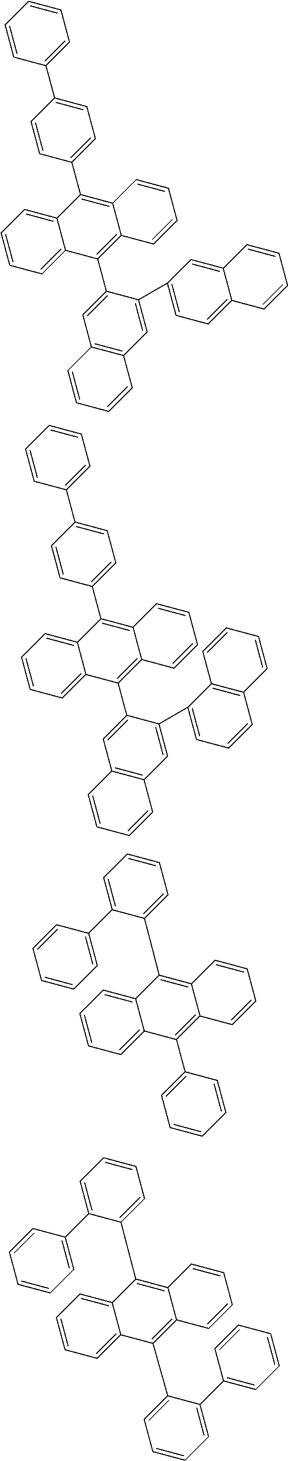

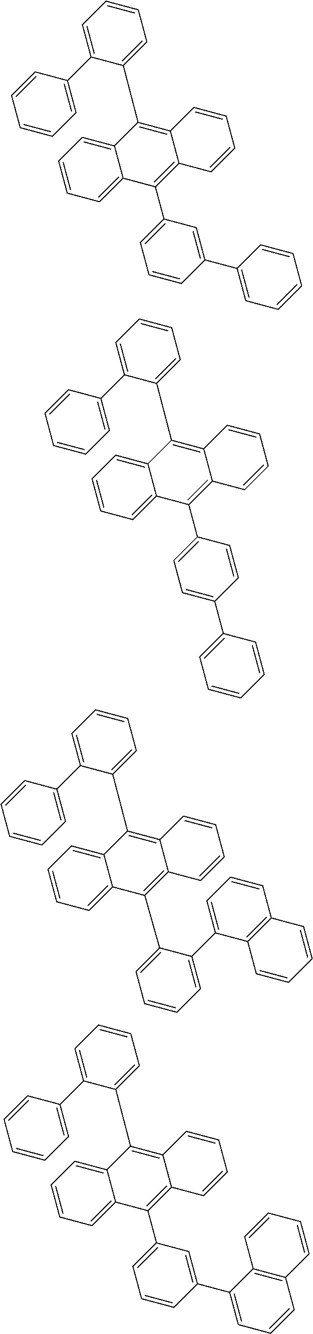

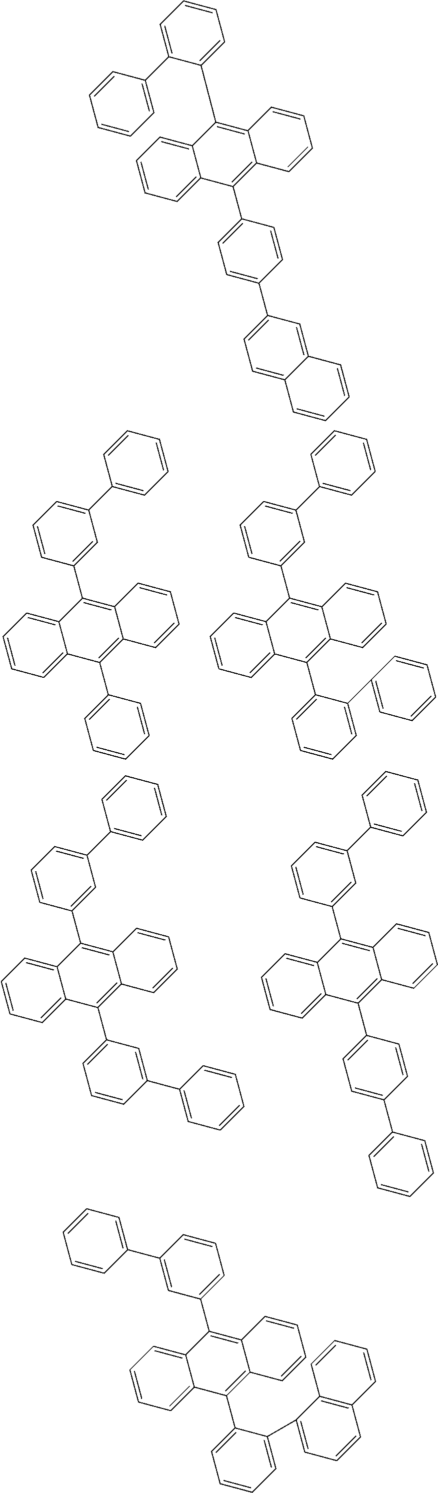

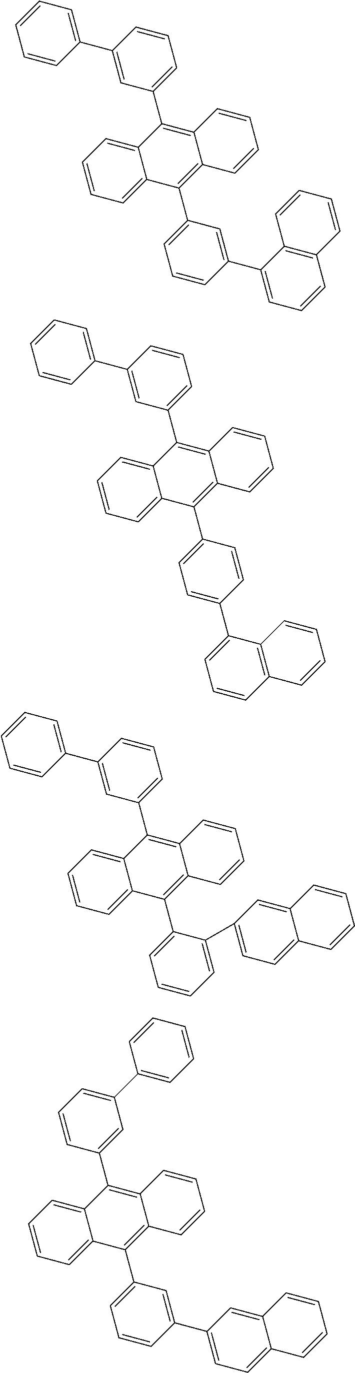

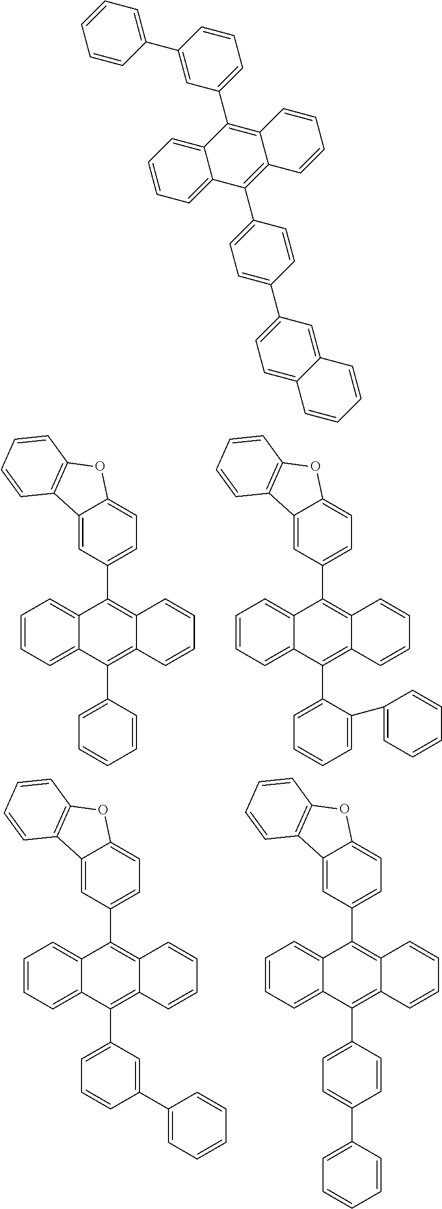

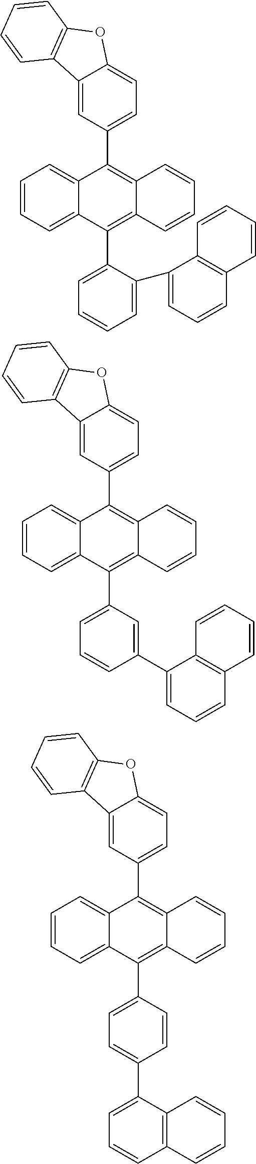

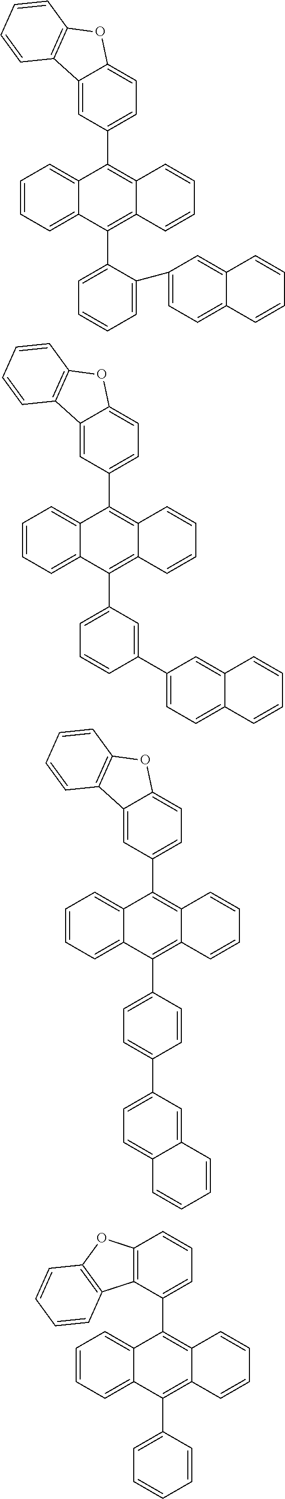

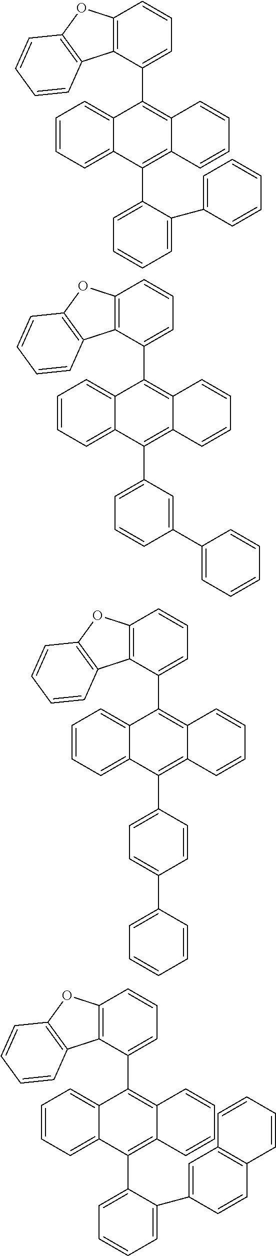

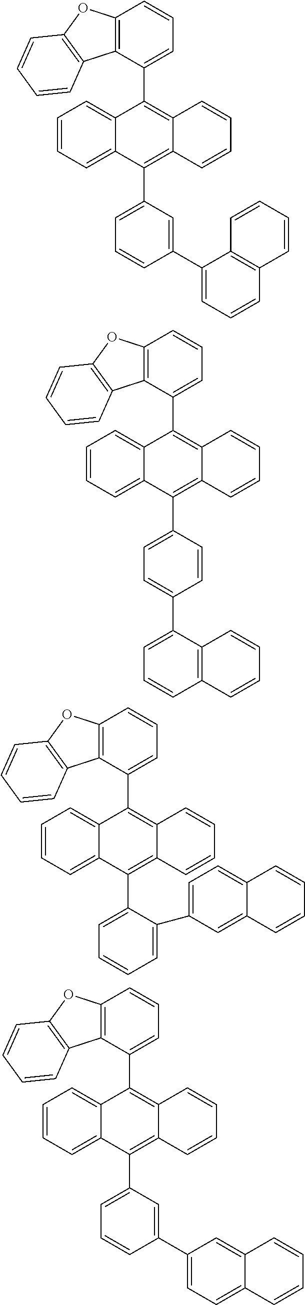

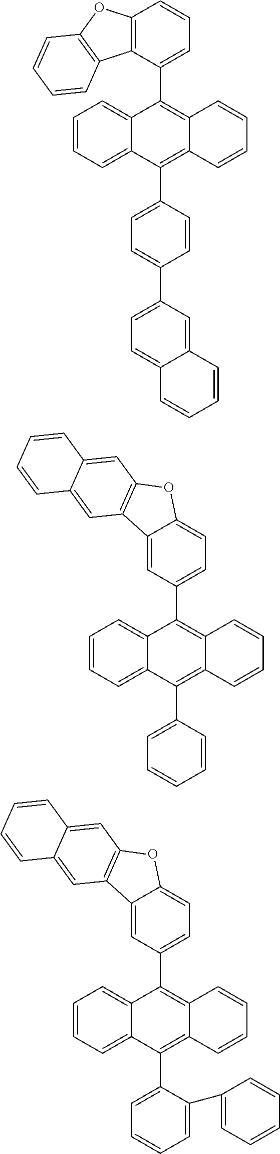 [SMILES: c1ccc2cc(-c3ccc(-c4c5ccccc5c(-c5cccc6oc7ccccc7c56)c5ccccc45)cc3)ccc2c1 ; c1ccc(-c2c3ccccc3c(-c3ccc4oc5cc6ccccc6cc5c4c3)c3ccccc23)cc1 ; c1ccc(-c2ccccc2-c2c3ccccc3c(-c3ccc4oc5cc6ccccc6cc5c4c3)c3ccccc23)cc1]

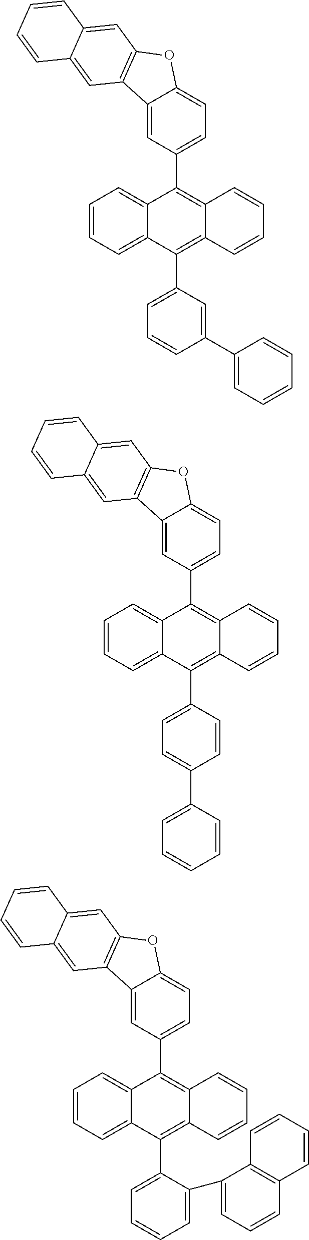 [SMILES: c1ccc(-c2cccc(-c3c4ccccc4c(-c4ccc5oc6cc7ccccc7cc6c5c4)c4ccccc34)c2)cc1 ; c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)c(-c2cccc3ccccc23)c1]

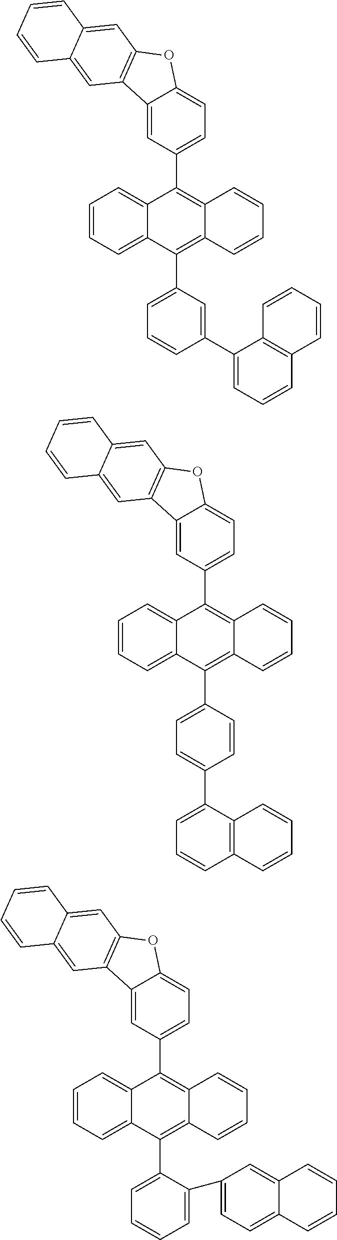 [SMILES: c1cc(-c2cccc3ccccc23)cc(-c2c3ccccc3c(-c3ccc4oc5cc6ccccc6cc5c4c3)c3ccccc23)c1 ; c1ccc2cc3c(cc2c1)oc1ccc(-c2c4ccccc4c(-c4ccc(-c5cccc6ccccc56)cc4)c4ccccc24)cc13 ; c1ccc(-c2c3ccccc3c(-c3ccc4oc5cc6ccccc6cc5c4c3)c3ccccc23)c(-c2ccc3ccccc3c2)c1]

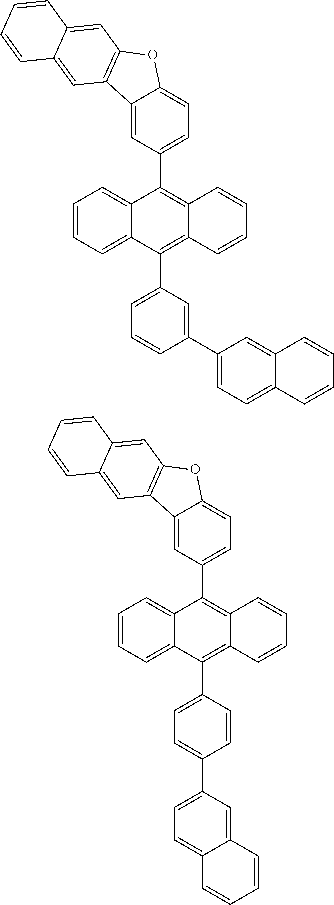 [SMILES: c1cc(-c2ccc3ccccc3c2)cc(-c2c3ccccc3c(-c3ccc4oc5cc6ccccc6cc5c4c3)c3ccccc23)c1 ; c1ccc2cc(-c3ccc(-c4c5ccccc5c(-c5ccc6oc7cc8ccccc8cc7c6c5)c5ccccc45)cc3)ccc2c1]

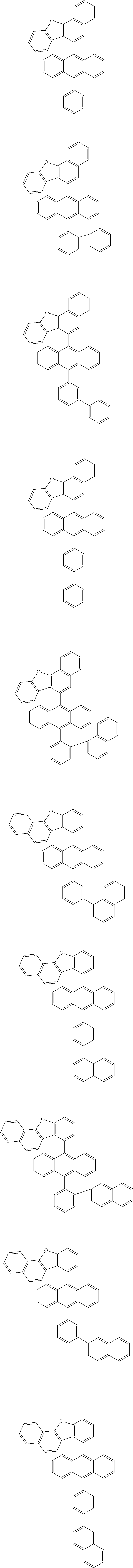

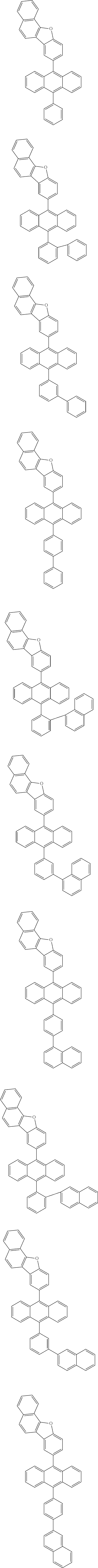

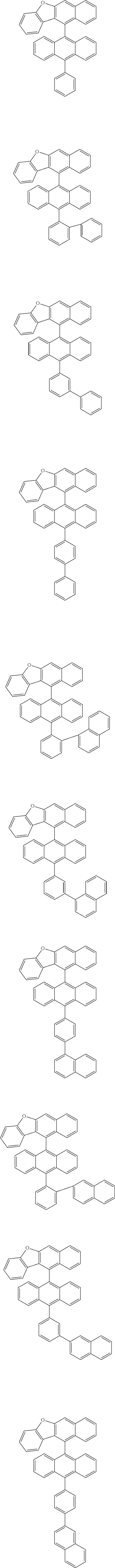

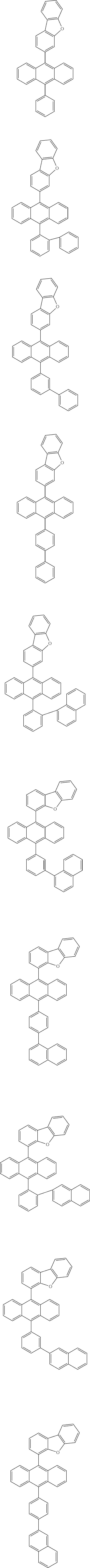

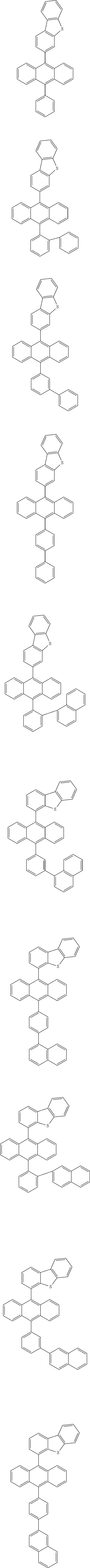

[chemical structure]

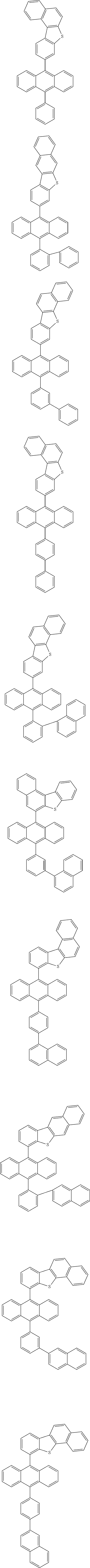

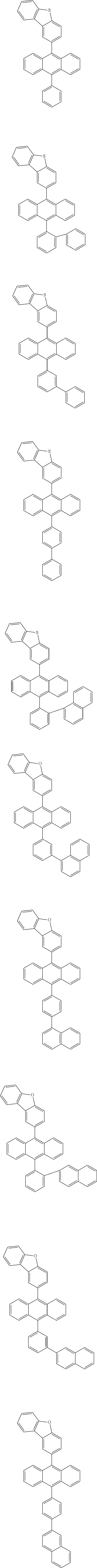

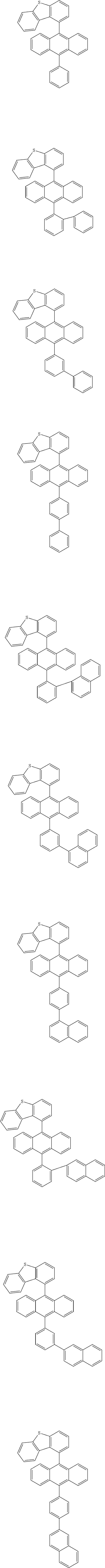

[chemical structure]

[chemical structure]

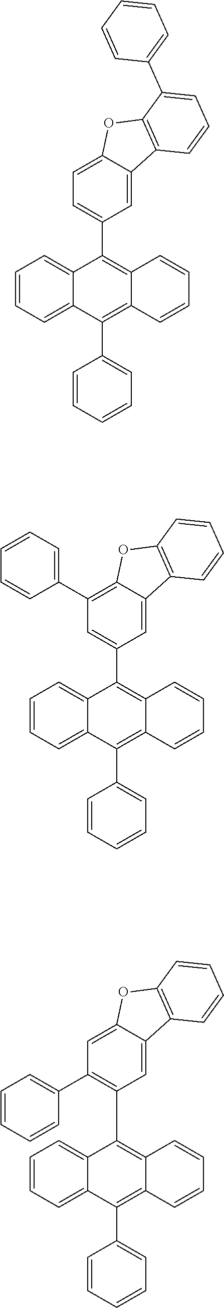 [SMILES: c1ccc(-c2c3ccccc3c(-c3ccc4oc5c(-c6ccccc6)cccc5c4c3)c3ccccc23)cc1 ; c1ccc(-c2c3ccccc3c(-c3cc(-c4ccccc4)c4oc5ccccc5c4c3)c3ccccc23)cc1 ; c1ccc(-c2cc3oc4ccccc4c3cc2-c2c3ccccc3c(-c3ccccc3)c3ccccc23)cc1]

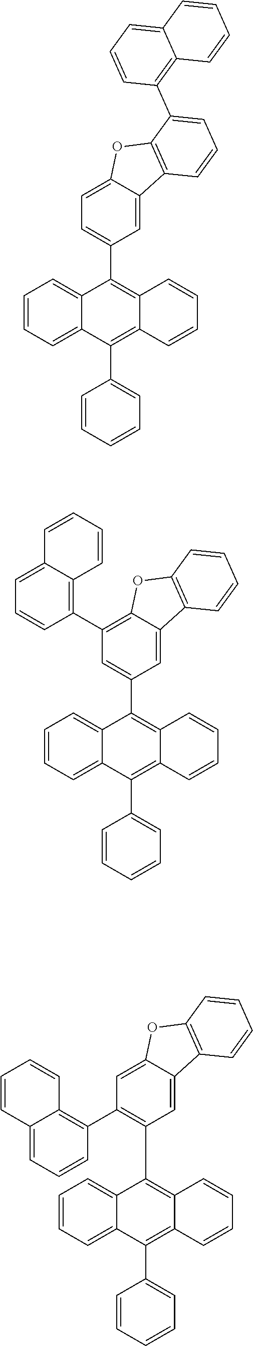 [SMILES: c1ccc(-c2c3ccccc3c(-c3ccc4oc5c(-c6cccc7ccccc67)cccc5c4c3)c3ccccc23)cc1 ; c1ccc(-c2c3ccccc3c(-c3cc(-c4cccc5ccccc45)c4oc5ccccc5c4c3)c3ccccc23)cc1 ; c1ccc(-c2c3ccccc3c(-c3cc4c(cc3-c3cccc5ccccc35)oc3ccccc34)c3ccccc23)cc1]

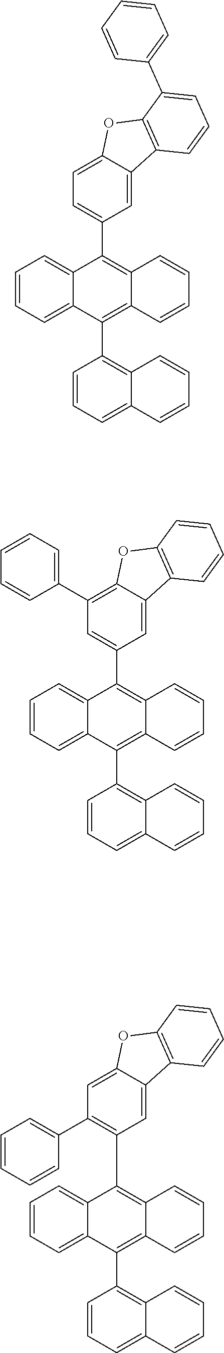 [SMILES: c1ccc(-c2cccc3c2oc2ccc(-c4c5ccccc5c(-c5cccc6ccccc56)c5ccccc45)cc23)cc1 ; c1ccc(-c2cc(-c3c4ccccc4c(-c4cccc5ccccc45)c4ccccc34)cc3c2oc2ccccc23)cc1 ; c1ccc(-c2cc3oc4ccccc4c3cc2-c2c3ccccc3c(-c3cccc4ccccc34)c3ccccc23)cc1]

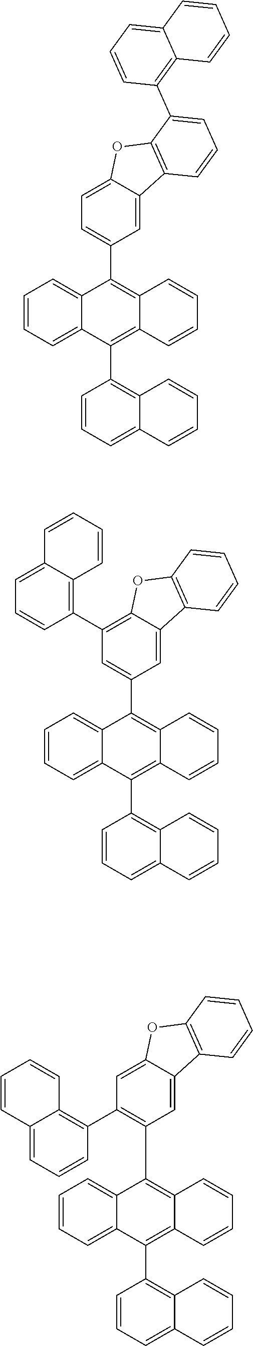 [SMILES: c1ccc2c(-c3c4ccccc4c(-c4ccc5oc6c(-c7cccc8ccccc78)cccc6c5c4)c4ccccc34)cccc2c1 ; c1ccc2c(-c3c4ccccc4c(-c4cc(-c5cccc6ccccc56)c5oc6ccccc6c5c4)c4ccccc34)cccc2c1 ; c1ccc2c(-c3cc4oc5ccccc5c4cc3-c3c4ccccc4c(-c4cccc5ccccc45)c4ccccc34)cccc2c1]

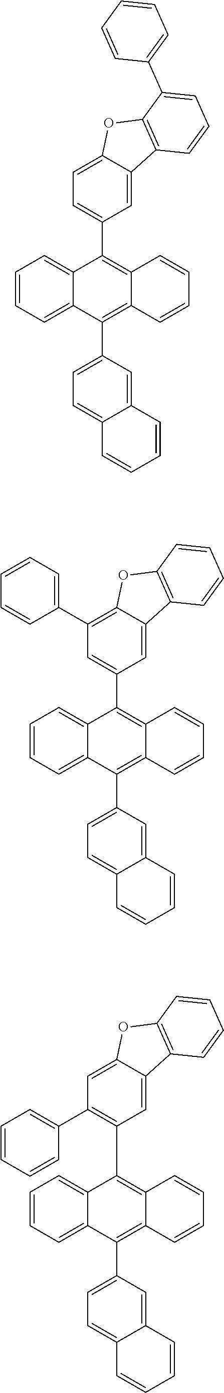 [SMILES: c1ccc(-c2cccc3c2oc2ccc(-c4c5ccccc5c(-c5ccc6ccccc6c5)c5ccccc45)cc23)cc1 ; c1ccc(-c2cc(-c3c4ccccc4c(-c4ccc5ccccc5c4)c4ccccc34)cc3c2oc2ccccc23)cc1 ; c1ccc(-c2cc3oc4ccccc4c3cc2-c2c3ccccc3c(-c3ccc4ccccc4c3)c3ccccc23)cc1]

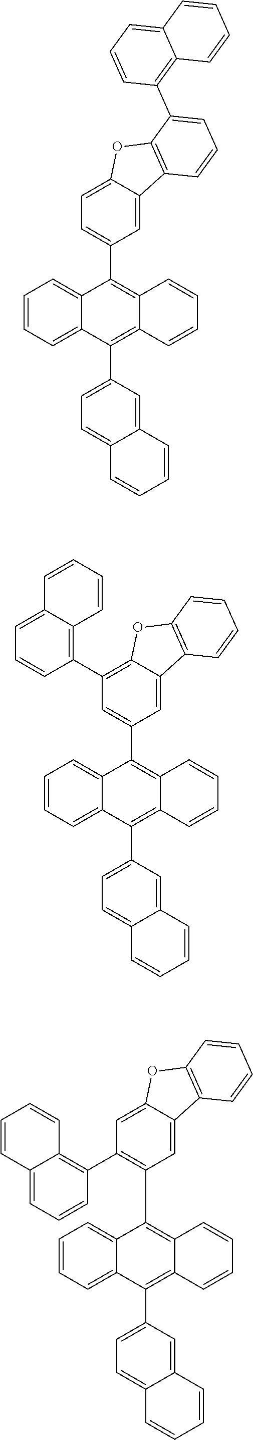 [SMILES: c1ccc2cc(-c3c4ccccc4c(-c4ccc5oc6c(-c7cccc8ccccc78)cccc6c5c4)c4ccccc34)ccc2c1 ; c1ccc2cc(-c3c4ccccc4c(-c4cc(-c5cccc6ccccc56)c5oc6ccccc6c5c4)c4ccccc34)ccc2c1 ; c1ccc2cc(-c3c4ccccc4c(-c4cc5c(cc4-c4cccc6ccccc46)oc4ccccc45)c4ccccc34)ccc2c1]

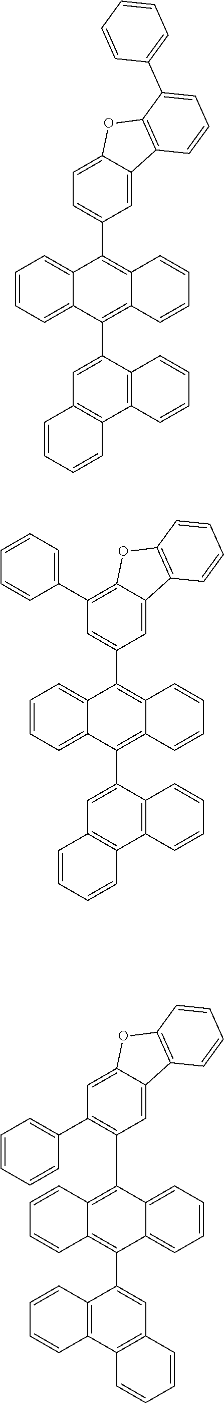 [SMILES: c1ccc(-c2cccc3c2oc2ccc(-c4c5ccccc5c(-c5cc6ccccc6c6ccccc56)c5ccccc45)cc23)cc1 ; c1ccc(-c2cc(-c3c4ccccc4c(-c4cc5ccccc5c5ccccc45)c4ccccc34)cc3c2oc2ccccc23)cc1 ; c1ccc(-c2cc3oc4ccccc4c3cc2-c2c3ccccc3c(-c3cc4ccccc4c4ccccc34)c3ccccc23)cc1]

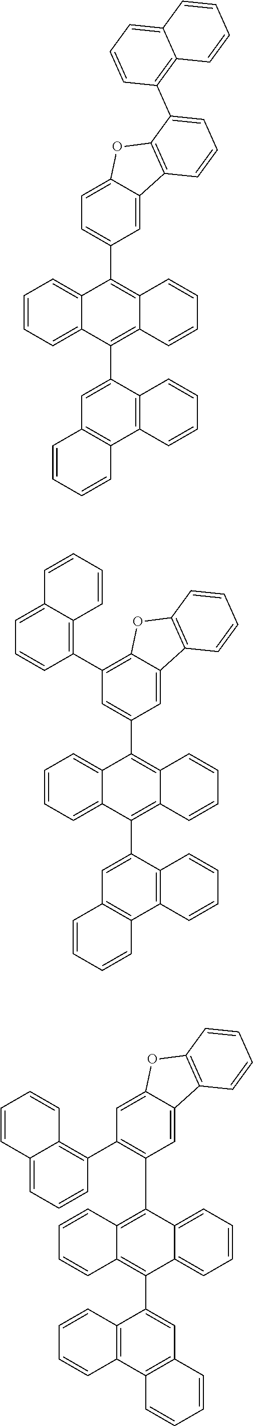 [SMILES: c1ccc2c(-c3cccc4c3oc3ccc(-c5c6ccccc6c(-c6cc7ccccc7c7ccccc67)c6ccccc56)cc34)cccc2c1 ; c1ccc2c(-c3cc(-c4c5ccccc5c(-c5cc6ccccc6c6ccccc56)c5ccccc45)cc4c3oc3ccccc34)cccc2c1 ; c1ccc2c(-c3cc4oc5ccccc5c4cc3-c3c4ccccc4c(-c4cc5ccccc5c5ccccc45)c4ccccc34)cccc2c1]

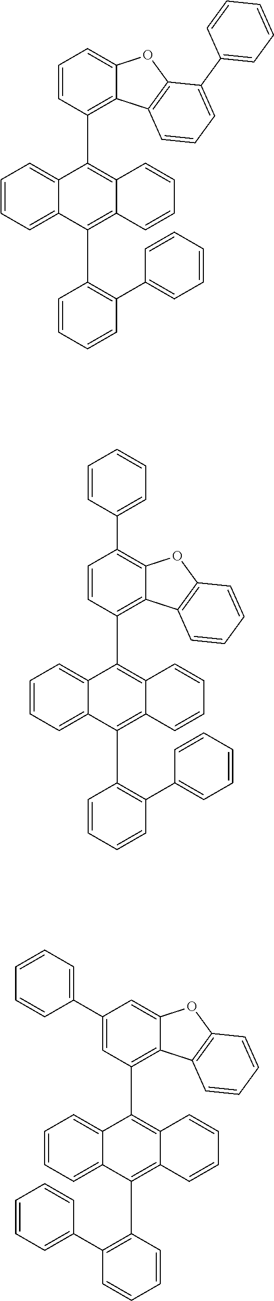 [SMILES: c1ccc(-c2ccccc2-c2c3ccccc3c(-c3cccc4oc5c(-c6ccccc6)cccc5c34)c3ccccc23)cc1 ; c1ccc(-c2ccccc2-c2c3ccccc3c(-c3ccc(-c4ccccc4)c4oc5ccccc5c34)c3ccccc23)cc1 ; c1ccc(-c2cc(-c3c4ccccc4c(-c4ccccc4-c4ccccc4)c4ccccc34)c3c(c2)oc2ccccc23)cc1]

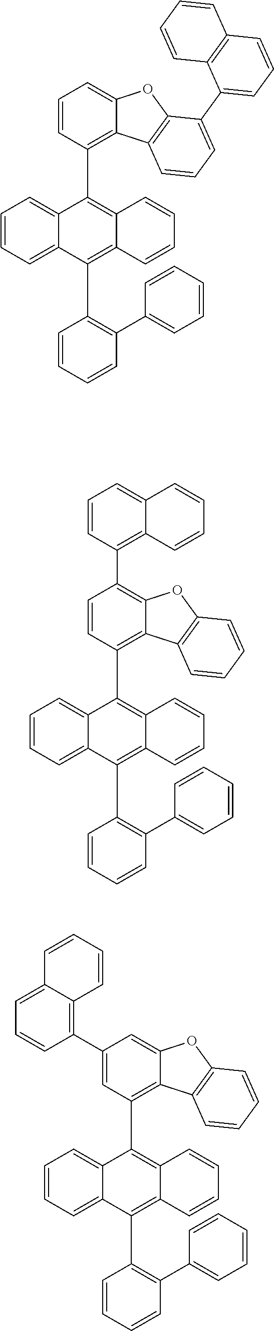 [SMILES: c1ccc(-c2ccccc2-c2c3ccccc3c(-c3cccc4oc5c(-c6cccc7ccccc67)cccc5c34)c3ccccc23)cc1 ; c1ccc(-c2ccccc2-c2c3ccccc3c(-c3ccc(-c4cccc5ccccc45)c4oc5ccccc5c34)c3ccccc23)cc1 ; c1ccc(-c2ccccc2-c2c3ccccc3c(-c3cc(-c4cccc5ccccc45)cc4oc5ccccc5c34)c3ccccc23)cc1]

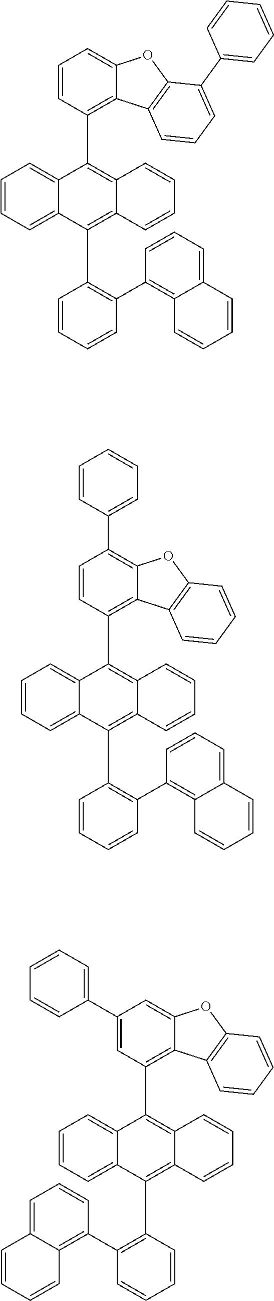 [SMILES: c1ccc(-c2cccc3c2oc2cccc(-c4c5ccccc5c(-c5ccccc5-c5cccc6ccccc56)c5ccccc45)c23)cc1 ; c1ccc(-c2ccc(-c3c4ccccc4c(-c4ccccc4-c4cccc5ccccc45)c4ccccc34)c3c2oc2ccccc23)cc1 ; c1ccc(-c2cc(-c3c4ccccc4c(-c4ccccc4-c4cccc5ccccc45)c4ccccc34)c3c(c2)oc2ccccc23)cc1]

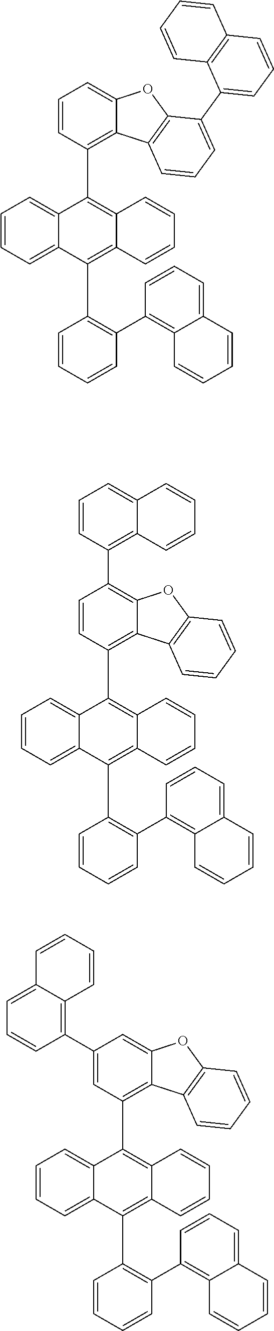 [SMILES: c1ccc(-c2c3ccccc3c(-c3cccc4oc5c(-c6cccc7ccccc67)cccc5c34)c3ccccc23)c(-c2cccc3ccccc23)c1 ; c1ccc(-c2c3ccccc3c(-c3ccc(-c4cccc5ccccc45)c4oc5ccccc5c34)c3ccccc23)c(-c2cccc3ccccc23)c1 ; c1ccc(-c2c3ccccc3c(-c3cc(-c4cccc5ccccc45)cc4oc5ccccc5c34)c3ccccc23)c(-c2cccc3ccccc23)c1]

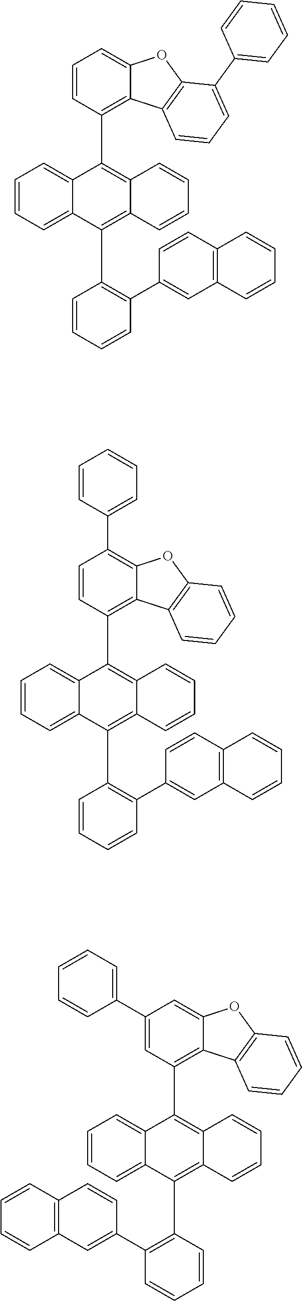 [SMILES: c1ccc(-c2cccc3c2oc2cccc(-c4c5ccccc5c(-c5ccccc5-c5ccc6ccccc6c5)c5ccccc45)c23)cc1 ; c1ccc(-c2ccc(-c3c4ccccc4c(-c4ccccc4-c4ccc5ccccc5c4)c4ccccc34)c3c2oc2ccccc23)cc1 ; c1ccc(-c2cc(-c3c4ccccc4c(-c4ccccc4-c4ccc5ccccc5c4)c4ccccc34)c3c(c2)oc2ccccc23)cc1]

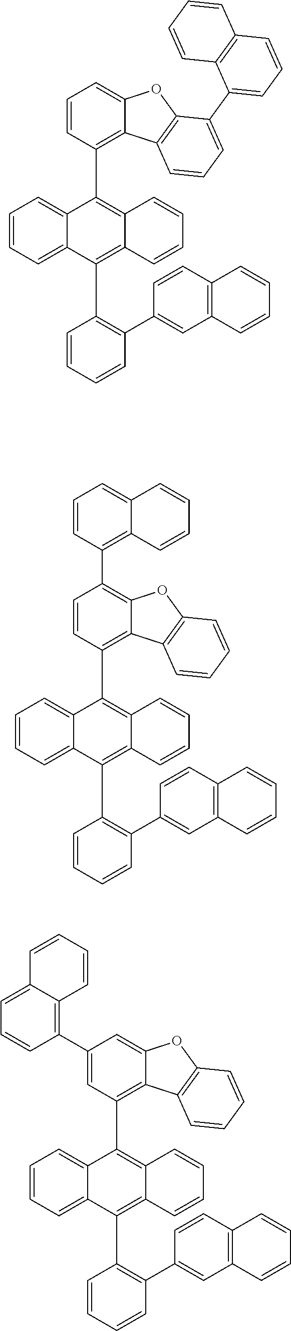 [SMILES: c1ccc(-c2c3ccccc3c(-c3cccc4oc5c(-c6cccc7ccccc67)cccc5c34)c3ccccc23)c(-c2ccc3ccccc3c2)c1 ; c1ccc(-c2c3ccccc3c(-c3ccc(-c4cccc5ccccc45)c4oc5ccccc5c34)c3ccccc23)c(-c2ccc3ccccc3c2)c1 ; c1ccc(-c2c3ccccc3c(-c3cc(-c4cccc5ccccc45)cc4oc5ccccc5c34)c3ccccc23)c(-c2ccc3ccccc3c2)c1]

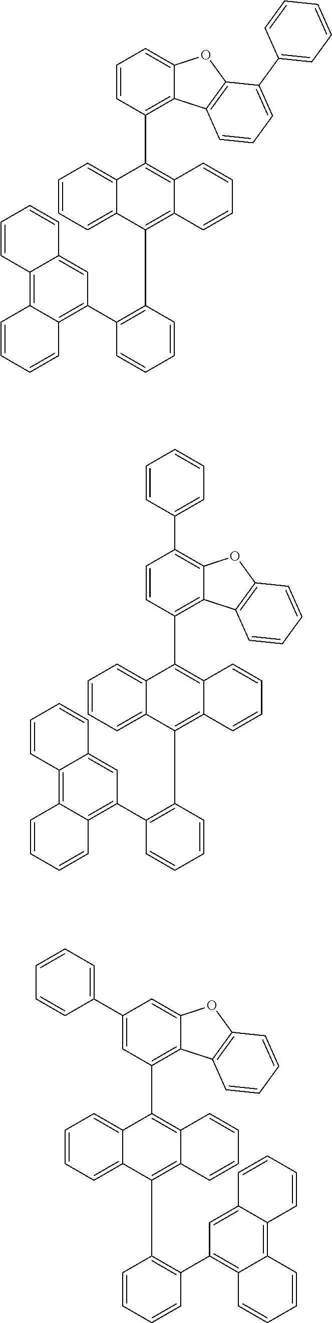 [SMILES: c1ccc(-c2cccc3c2oc2cccc(-c4c5ccccc5c(-c5ccccc5-c5cc6ccccc6c6ccccc56)c5ccccc45)c23)cc1 ; c1ccc(-c2ccc(-c3c4ccccc4c(-c4ccccc4-c4cc5ccccc5c5ccccc45)c4ccccc34)c3c2oc2ccccc23)cc1 ; c1ccc(-c2cc(-c3c4ccccc4c(-c4ccccc4-c4cc5ccccc5c5ccccc45)c4ccccc34)c3c(c2)oc2ccccc23)cc1]

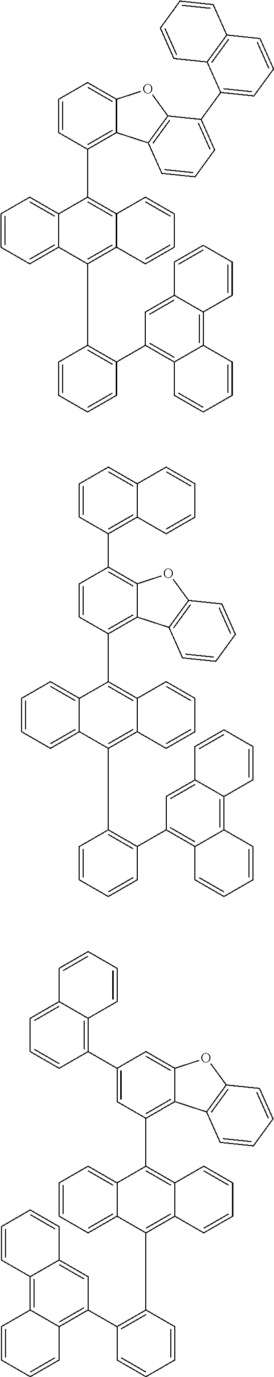 [SMILES: c1ccc(-c2cc3ccccc3c3ccccc23)c(-c2c3ccccc3c(-c3cccc4oc5c(-c6cccc7ccccc67)cccc5c34)c3ccccc23)c1 ; c1ccc(-c2cc3ccccc3c3ccccc23)c(-c2c3ccccc3c(-c3ccc(-c4cccc5ccccc45)c4oc5ccccc5c34)c3ccccc23)c1 ; c1ccc(-c2cc3ccccc3c3ccccc23)c(-c2c3ccccc3c(-c3cc(-c4cccc5ccccc45)cc4oc5ccccc5c34)c3ccccc23)c1]

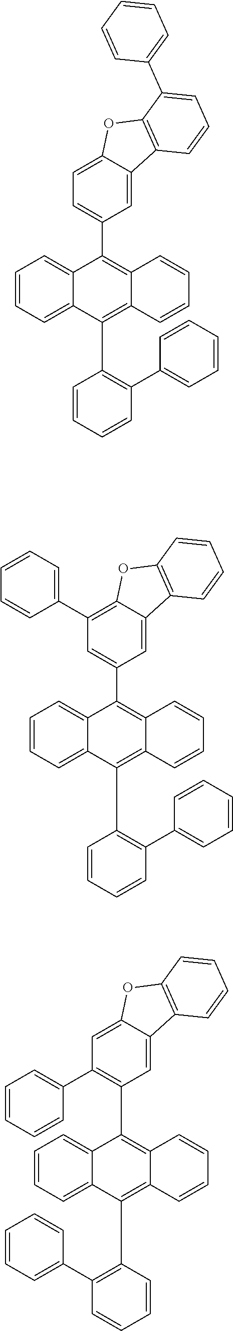 [SMILES: c1ccc(-c2ccccc2-c2c3ccccc3c(-c3ccc4oc5c(-c6ccccc6)cccc5c4c3)c3ccccc23)cc1 ; c1ccc(-c2ccccc2-c2c3ccccc3c(-c3cc(-c4ccccc4)c4oc5ccccc5c4c3)c3ccccc23)cc1 ; c1ccc(-c2ccccc2-c2c3ccccc3c(-c3cc4c(cc3-c3ccccc3)oc3ccccc34)c3ccccc23)cc1]

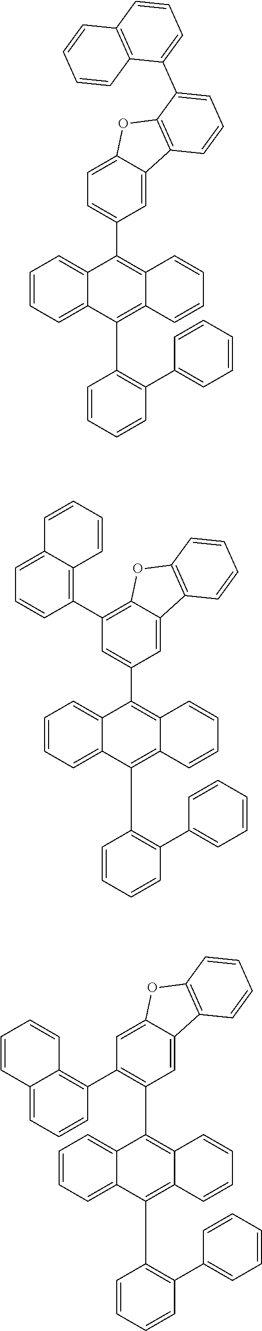 [SMILES: c1ccc(-c2ccccc2-c2c3ccccc3c(-c3ccc4oc5c(-c6cccc7ccccc67)cccc5c4c3)c3ccccc23)cc1 ; c1ccc(-c2ccccc2-c2c3ccccc3c(-c3cc(-c4cccc5ccccc45)c4oc5ccccc5c4c3)c3ccccc23)cc1 ; c1ccc(-c2ccccc2-c2c3ccccc3c(-c3cc4c(cc3-c3cccc5ccccc35)oc3ccccc34)c3ccccc23)cc1]

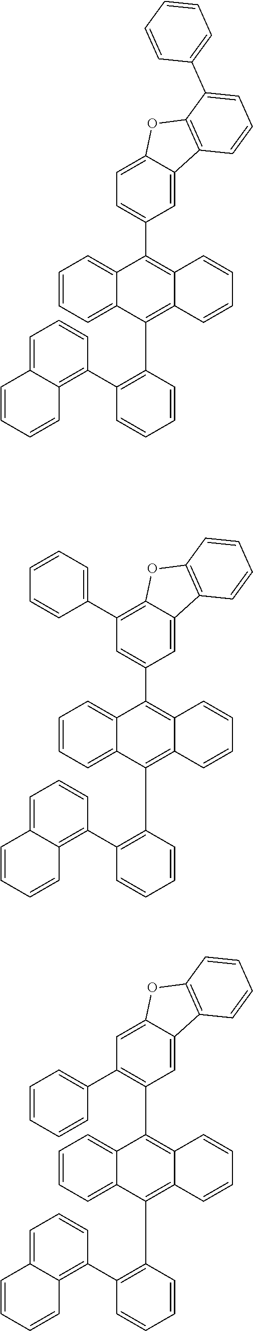 [SMILES: c1ccc(-c2cccc3c2oc2ccc(-c4c5ccccc5c(-c5ccccc5-c5cccc6ccccc56)c5ccccc45)cc23)cc1 ; c1ccc(-c2cc(-c3c4ccccc4c(-c4ccccc4-c4cccc5ccccc45)c4ccccc34)cc3c2oc2ccccc23)cc1 ; c1ccc(-c2cc3oc4ccccc4c3cc2-c2c3ccccc3c(-c3ccccc3-c3cccc4ccccc34)c3ccccc23)cc1]

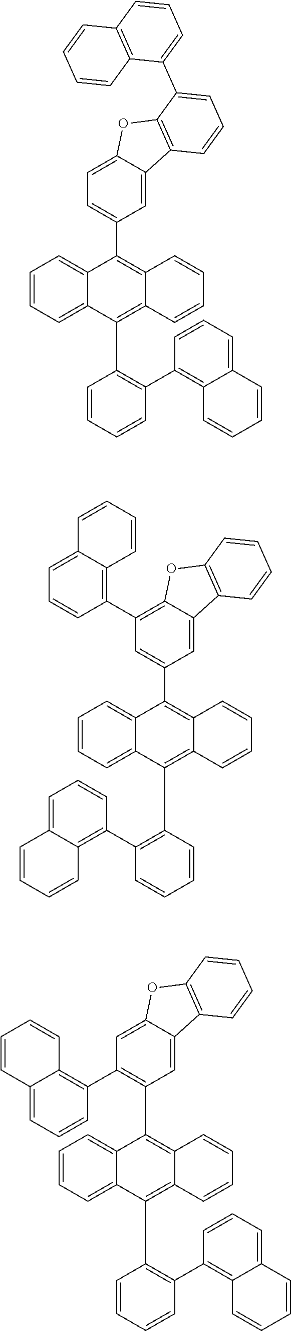 [SMILES: c1ccc(-c2c3ccccc3c(-c3ccc4oc5c(-c6cccc7ccccc67)cccc5c4c3)c3ccccc23)c(-c2cccc3ccccc23)c1 ; c1ccc(-c2c3ccccc3c(-c3cc(-c4cccc5ccccc45)c4oc5ccccc5c4c3)c3ccccc23)c(-c2cccc3ccccc23)c1 ; c1ccc(-c2c3ccccc3c(-c3cc4c(cc3-c3cccc5ccccc35)oc3ccccc34)c3ccccc23)c(-c2cccc3ccccc23)c1]

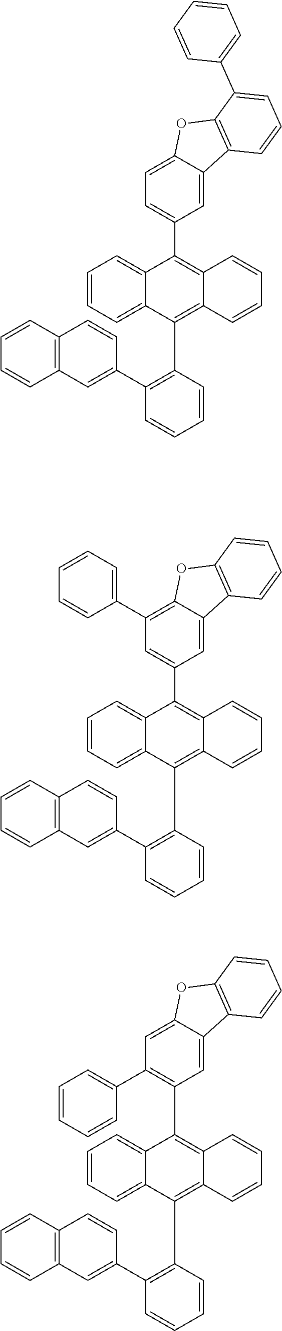 [SMILES: c1ccc(-c2cccc3c2oc2ccc(-c4c5ccccc5c(-c5ccccc5-c5ccc6ccccc6c5)c5ccccc45)cc23)cc1 ; c1ccc(-c2cc(-c3c4ccccc4c(-c4ccccc4-c4ccc5ccccc5c4)c4ccccc34)cc3c2oc2ccccc23)cc1 ; c1ccc(-c2cc3oc4ccccc4c3cc2-c2c3ccccc3c(-c3ccccc3-c3ccc4ccccc4c3)c3ccccc23)cc1]

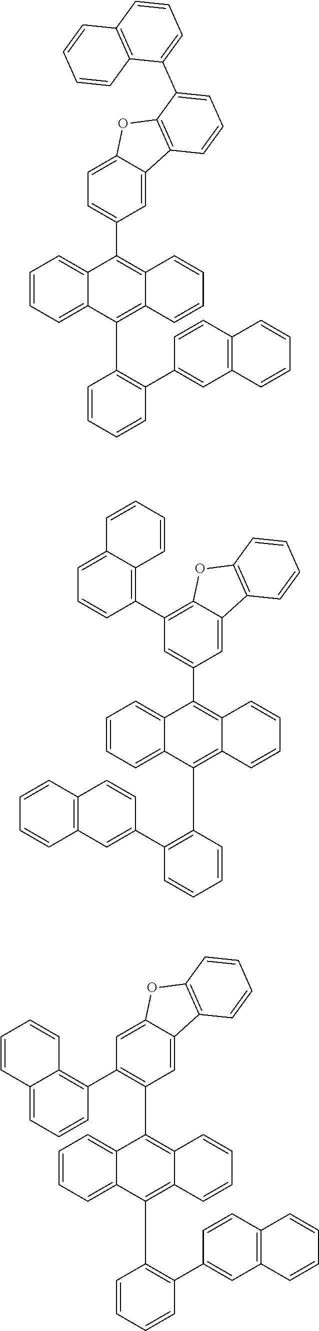 [SMILES: c1ccc(-c2c3ccccc3c(-c3ccc4oc5c(-c6cccc7ccccc67)cccc5c4c3)c3ccccc23)c(-c2ccc3ccccc3c2)c1 ; c1ccc(-c2c3ccccc3c(-c3cc(-c4cccc5ccccc45)c4oc5ccccc5c4c3)c3ccccc23)c(-c2ccc3ccccc3c2)c1 ; c1ccc(-c2c3ccccc3c(-c3cc4c(cc3-c3cccc5ccccc35)oc3ccccc34)c3ccccc23)c(-c2ccc3ccccc3c2)c1]

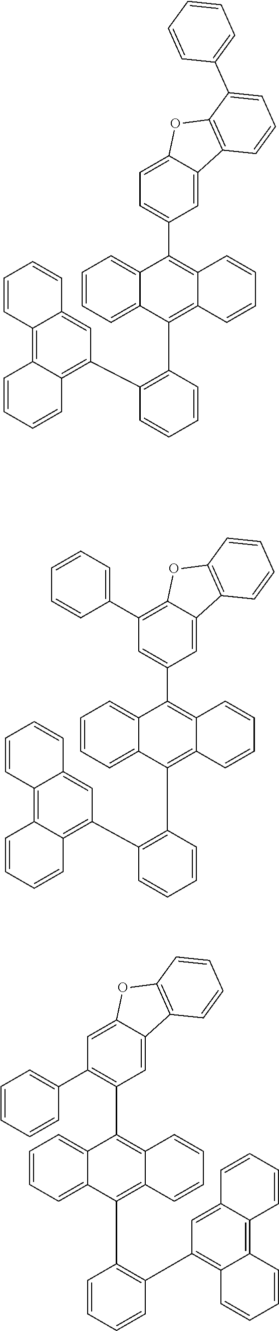 [SMILES: c1ccc(-c2cccc3c2oc2ccc(-c4c5ccccc5c(-c5ccccc5-c5cc6ccccc6c6ccccc56)c5ccccc45)cc23)cc1 ; c1ccc(-c2cc(-c3c4ccccc4c(-c4ccccc4-c4cc5ccccc5c5ccccc45)c4ccccc34)cc3c2oc2ccccc23)cc1 ; c1ccc(-c2cc3oc4ccccc4c3cc2-c2c3ccccc3c(-c3ccccc3-c3cc4ccccc4c4ccccc34)c3ccccc23)cc1]

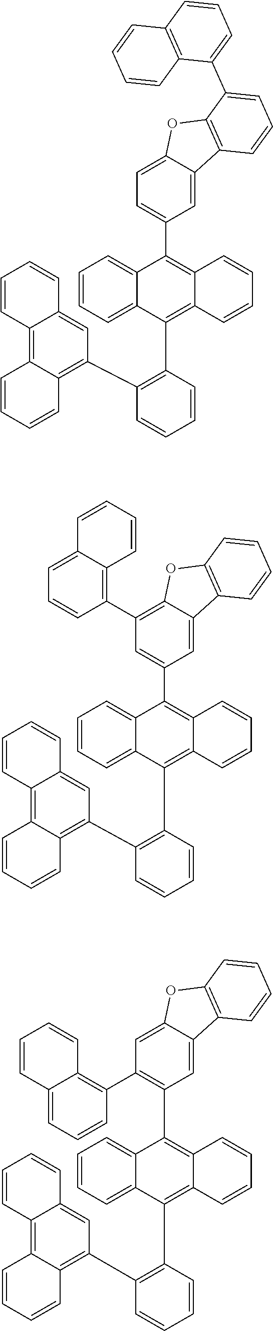 [SMILES: c1ccc(-c2cc3ccccc3c3ccccc23)c(-c2c3ccccc3c(-c3ccc4oc5c(-c6cccc7ccccc67)cccc5c4c3)c3ccccc23)c1 ; c1ccc(-c2cc3ccccc3c3ccccc23)c(-c2c3ccccc3c(-c3cc(-c4cccc5ccccc45)c4oc5ccccc5c4c3)c3ccccc23)c1 ; c1ccc(-c2cc3ccccc3c3ccccc23)c(-c2c3ccccc3c(-c3cc4c(cc3-c3cccc5ccccc35)oc3ccccc34)c3ccccc23)c1]

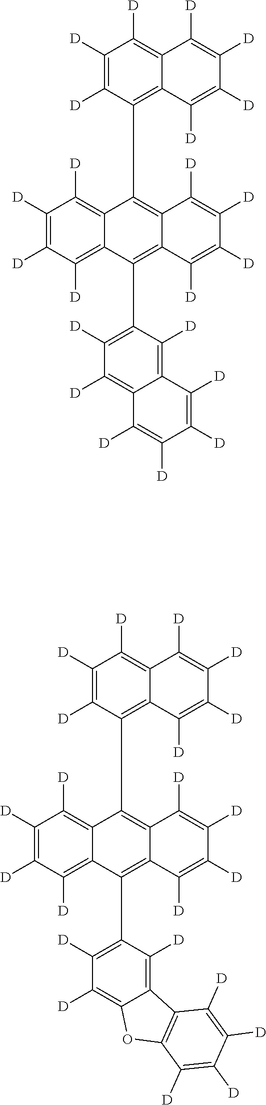 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H]]

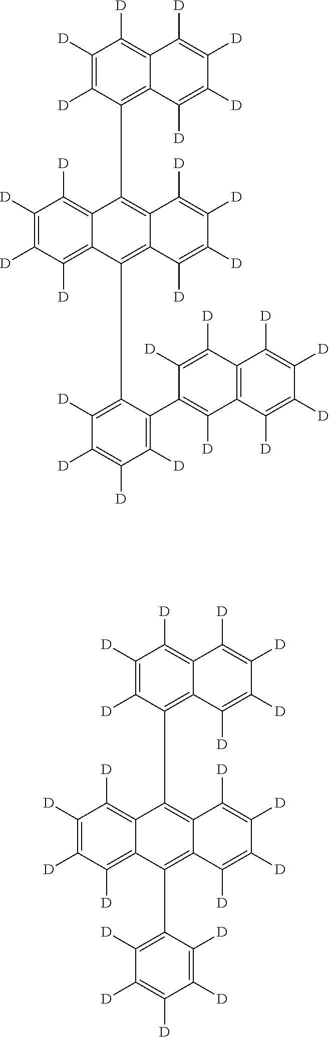 [SMILES: [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c(-c2c([2H])c([2H])c3c([2H])c([2H])c([2H])c([2H])c3c2[2H])c1[2H] ; [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c1[2H]]

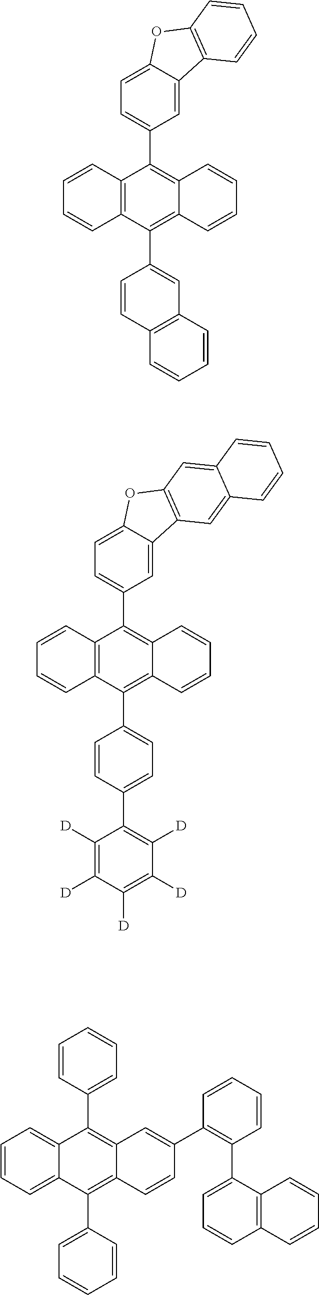

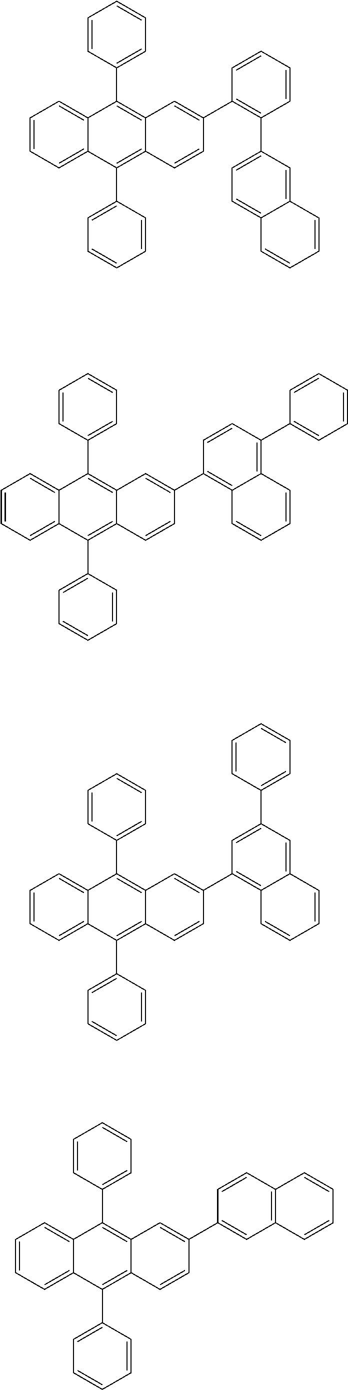

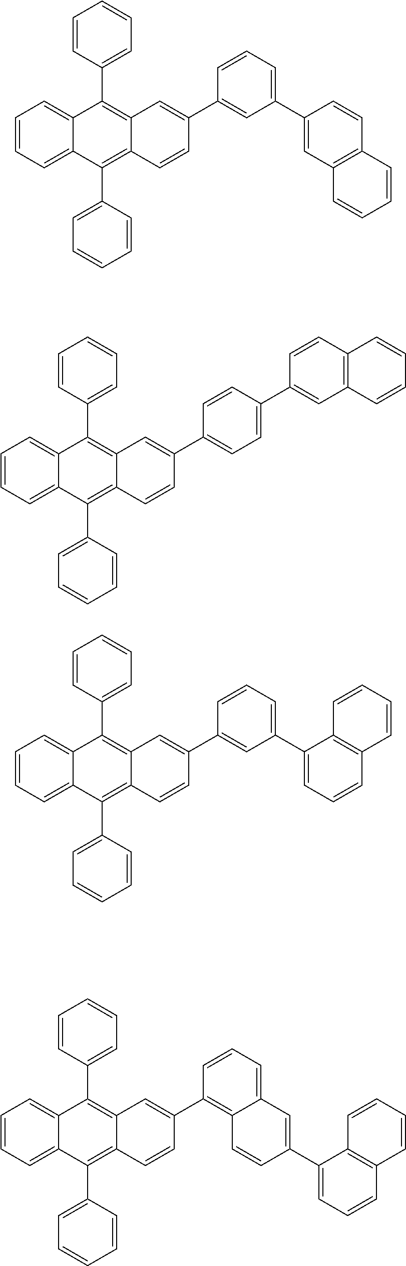

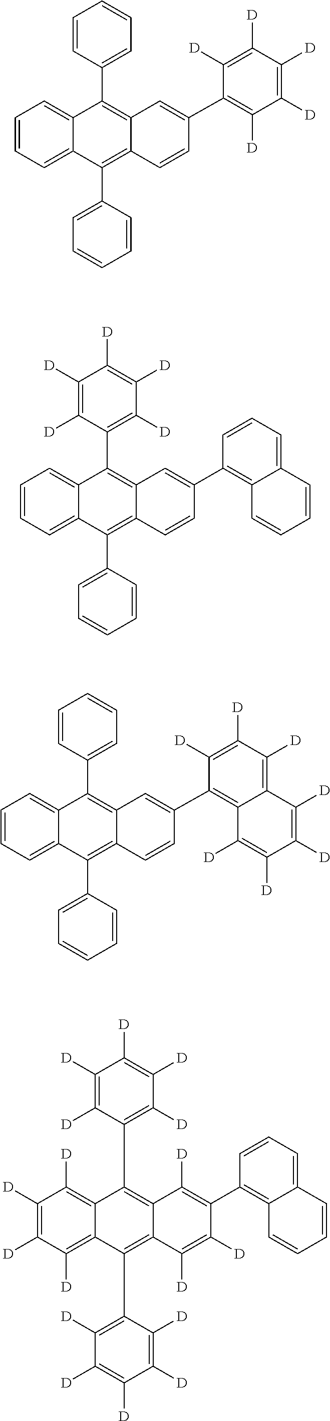 [SMILES: [2H]c1c([2H])c([2H])c(-c2ccc3c(-c4ccccc4)c4ccccc4c(-c4ccccc4)c3c2)c([2H])c1[2H] ; [2H]c1c([2H])c([2H])c(-c2c3ccccc3c(-c3ccccc3)c3ccc(-c4cccc5ccccc45)cc23)c([2H])c1[2H] ; [2H]c1c([2H])c([2H])c2c(-c3ccc4c(-c5ccccc5)c5ccccc5c(-c5ccccc5)c4c3)c([2H])c([2H])c([2H])c2c1[2H] ; [2H]c1c([2H])c([2H])c(-c2c3c([2H])c([2H])c([2H])c([2H])c3c(-c3c([2H])c([2H])c([2H])c([2H])c3[2H])c3c([2H])c(-c4cccc5ccccc45)c([2H])c([2H])c23)c([2H])c1[2H]]

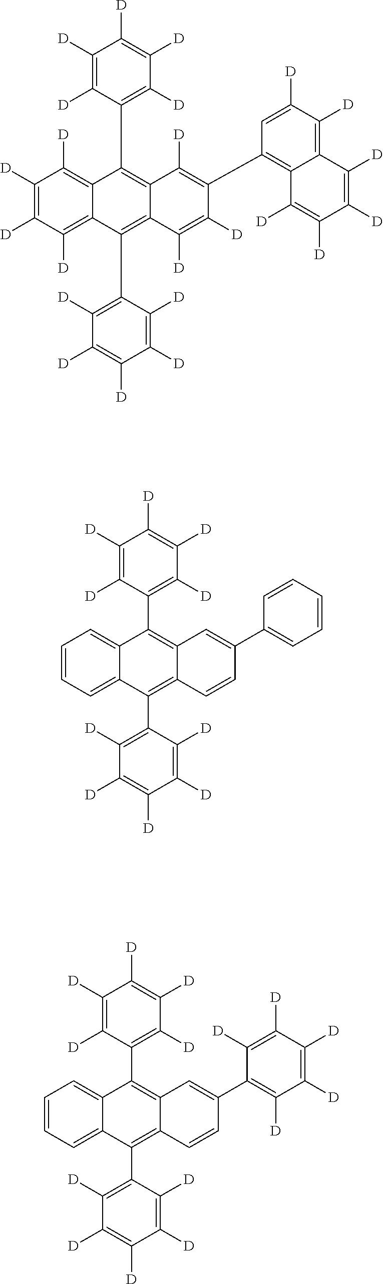 [SMILES: [2H]c1cc(-c2c([2H])c([2H])c3c(-c4c([2H])c([2H])c([2H])c([2H])c4[2H])c4c([2H])c([2H])c([2H])c([2H])c4c(-c4c([2H])c([2H])c([2H])c([2H])c4[2H])c3c2[2H])c2c([2H])c([2H])c([2H])c([2H])c2c1[2H] ; [2H]c1c([2H])c([2H])c(-c2c3ccccc3c(-c3c([2H])c([2H])c([2H])c([2H])c3[2H])c3cc(-c4ccccc4)ccc23)c([2H])c1[2H] ; [2H]c1c([2H])c([2H])c(-c2ccc3c(-c4c([2H])c([2H])c([2H])c([2H])c4[2H])c4ccccc4c(-c4c([2H])c([2H])c([2H])c([2H])c4[2H])c3c2)c([2H])c1[2H]]

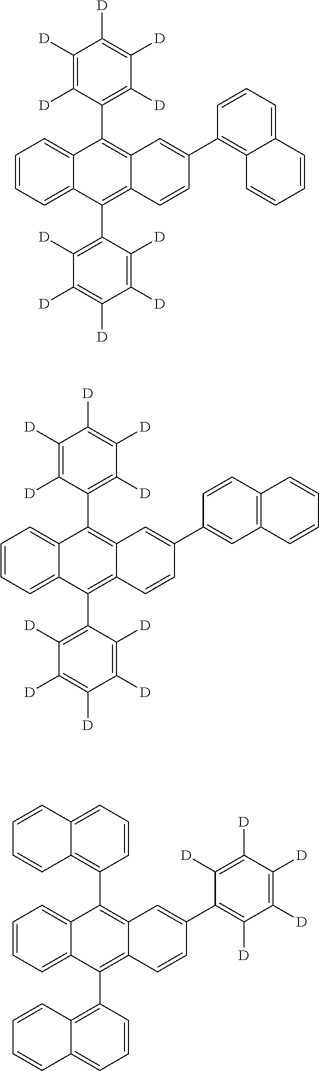 [SMILES: [2H]c1c([2H])c([2H])c(-c2c3ccccc3c(-c3c([2H])c([2H])c([2H])c([2H])c3[2H])c3cc(-c4cccc5ccccc45)ccc23)c([2H])c1[2H] ; [2H]c1c([2H])c([2H])c(-c2c3ccccc3c(-c3c([2H])c([2H])c([2H])c([2H])c3[2H])c3cc(-c4ccc5ccccc5c4)ccc23)c([2H])c1[2H] ; [2H]c1c([2H])c([2H])c(-c2ccc3c(-c4cccc5ccccc45)c4ccccc4c(-c4cccc5ccccc45)c3c2)c([2H])c1[2H]]

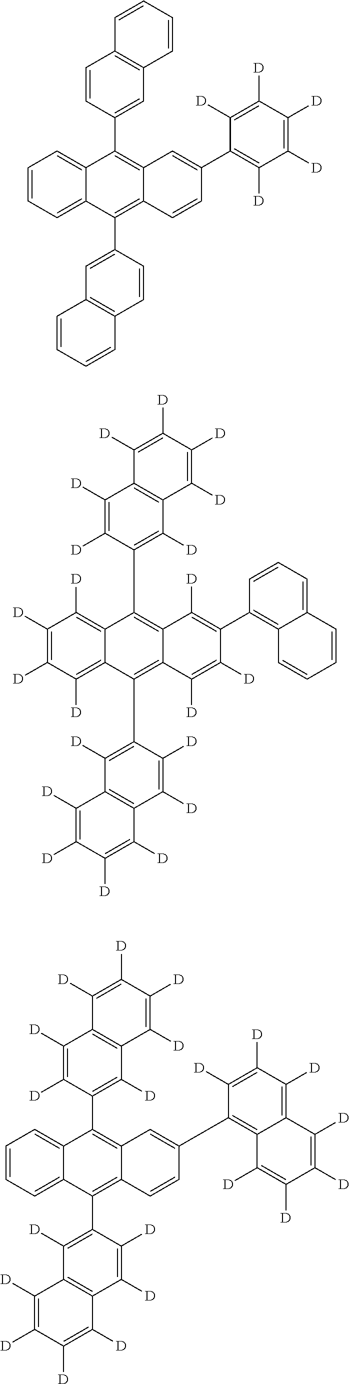 [SMILES: [2H]c1c([2H])c([2H])c(-c2ccc3c(-c4ccc5ccccc5c4)c4ccccc4c(-c4ccc5ccccc5c4)c3c2)c([2H])c1[2H] ; [2H]c1c([2H])c([2H])c2c([2H])c(-c3c4c([2H])c([2H])c([2H])c([2H])c4c(-c4c([2H])c([2H])c5c([2H])c([2H])c([2H])c([2H])c5c4[2H])c4c([2H])c(-c5cccc6ccccc56)c([2H])c([2H])c34)c([2H])c([2H])c2c1[2H] ; [2H]c1c([2H])c([2H])c2c([2H])c(-c3c4ccccc4c(-c4c([2H])c([2H])c5c([2H])c([2H])c([2H])c([2H])c5c4[2H])c4cc(-c5c([2H])c([2H])c([2H])c6c([2H])c([2H])c([2H])c([2H])c56)ccc34)c([2H])c([2H])c2c1[2H]]

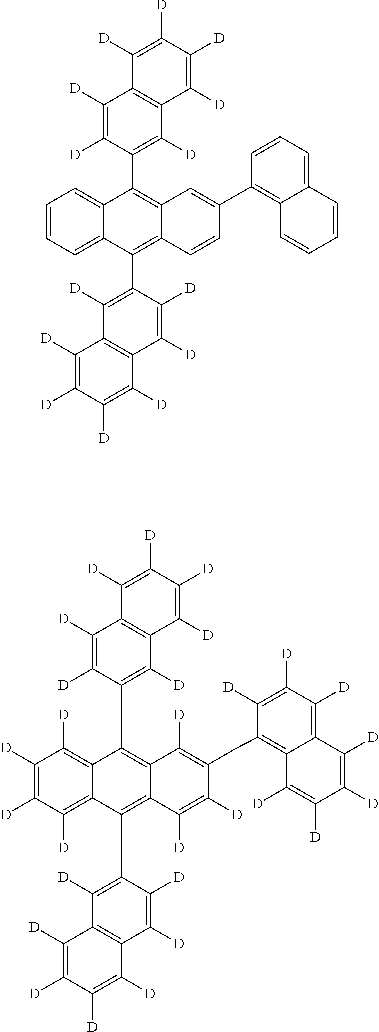 [SMILES: [2H]c1c([2H])c([2H])c2c([2H])c(-c3c4ccccc4c(-c4c([2H])c([2H])c5c([2H])c([2H])c([2H])c([2H])c5c4[2H])c4cc(-c5cccc6ccccc56)ccc34)c([2H])c([2H])c2c1[2H] ; [2H]c1c([2H])c([2H])c2c([2H])c(-c3c4c([2H])c([2H])c([2H])c([2H])c4c(-c4c([2H])c([2H])c5c([2H])c([2H])c([2H])c([2H])c5c4[2H])c4c([2H])c(Cc5c([2H])c([2H])c([2H])c6c([2H])c([2H])c([2H])c([2H])c56)c([2H])c([2H])c34)c([2H])c([2H])c2c1[2H]]

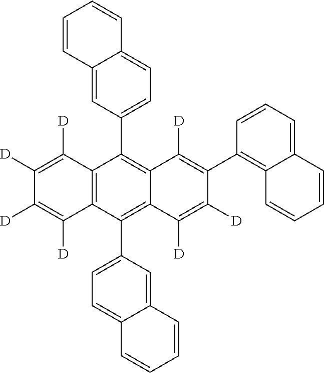 [SMILES: [2H]c1c([2H])c([2H])c2c(-c3ccc4ccccc4c3)c3c([2H])c(-c4cccc5ccccc45)c([2H])c([2H])c3c(-c3ccc4ccccc4c3)c2c1[2H]]

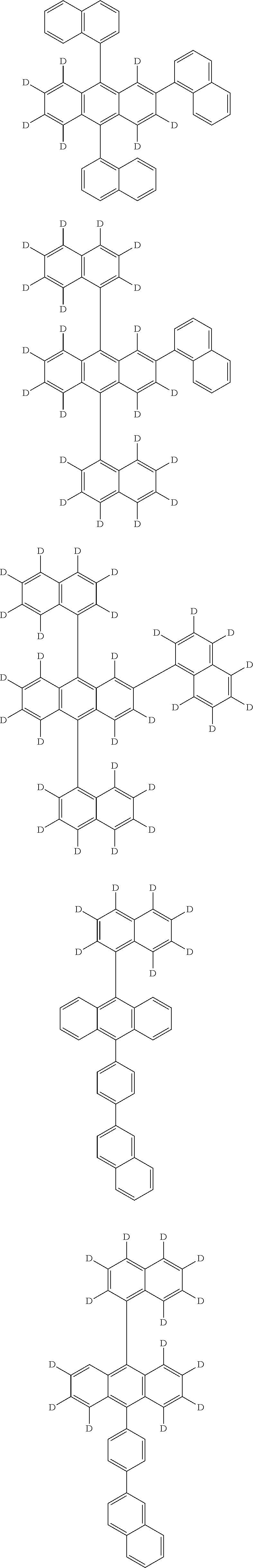

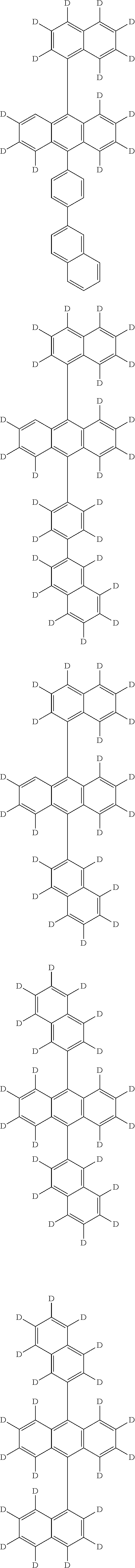

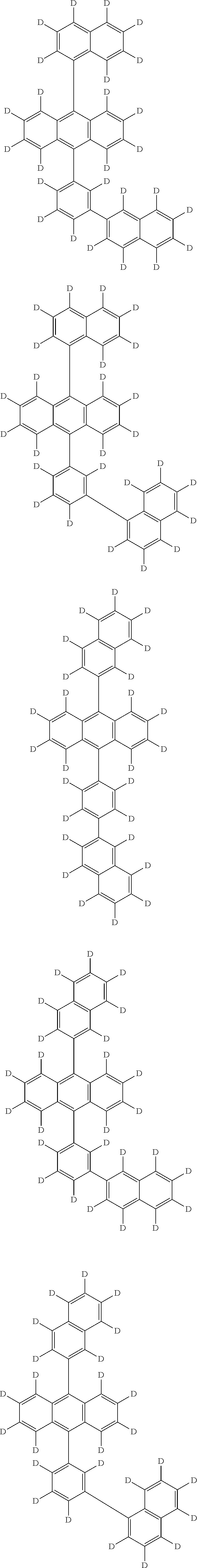

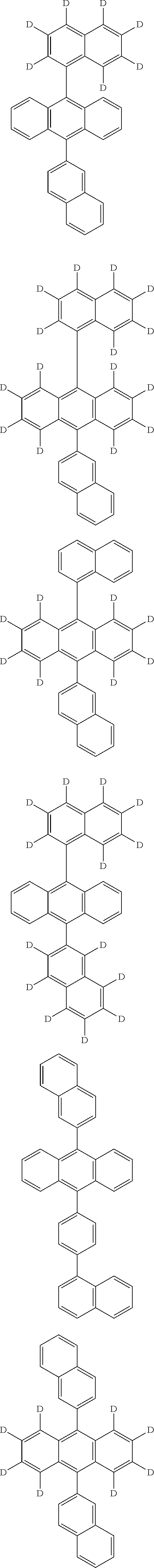

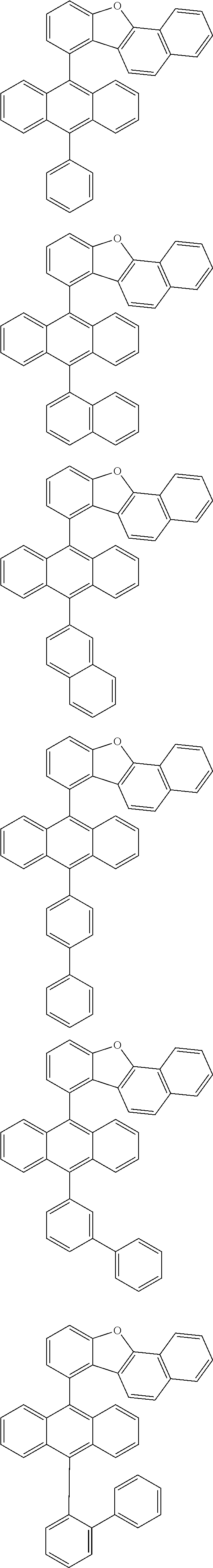

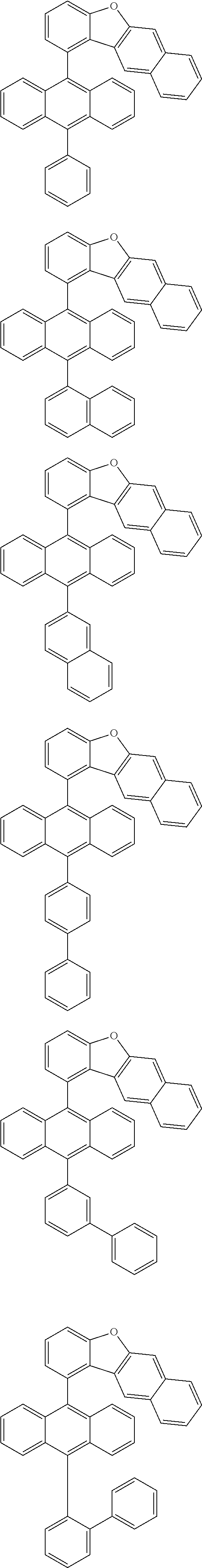

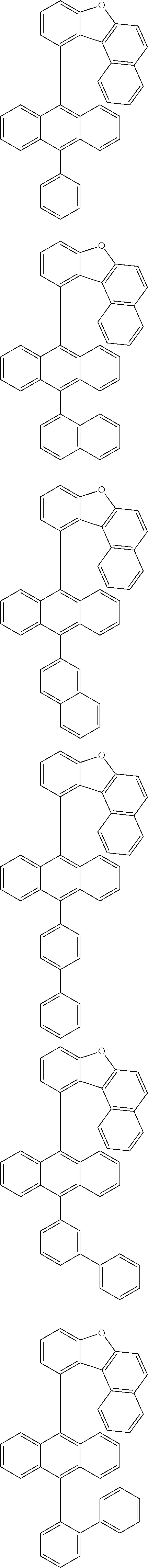

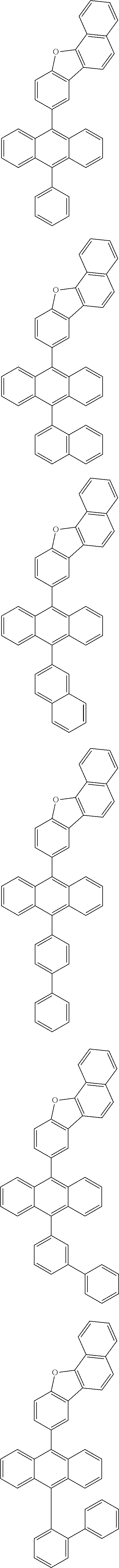

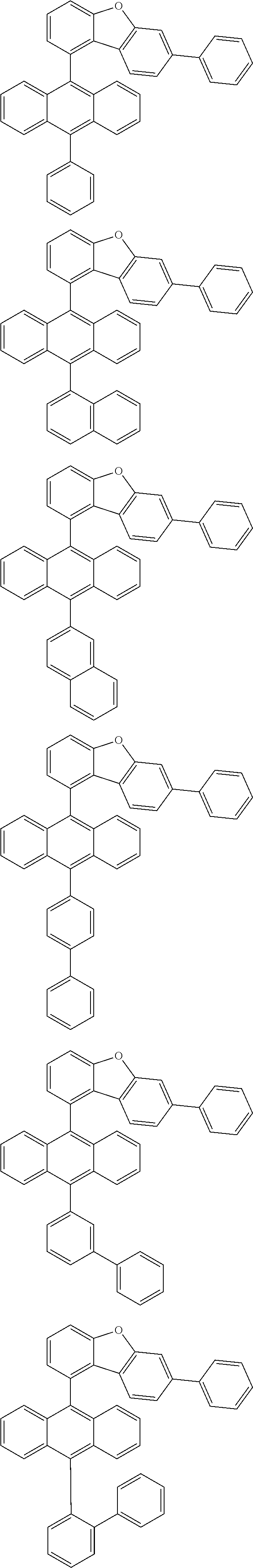

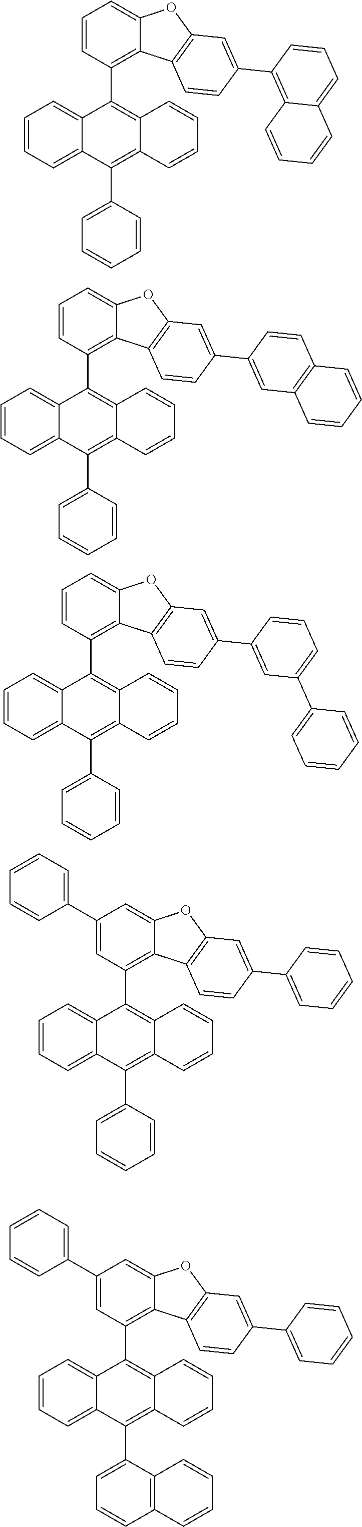

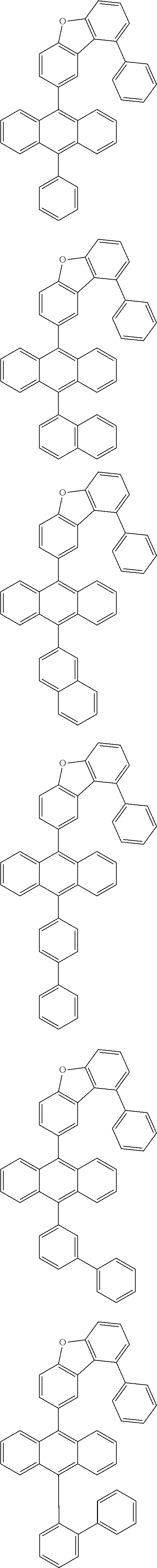

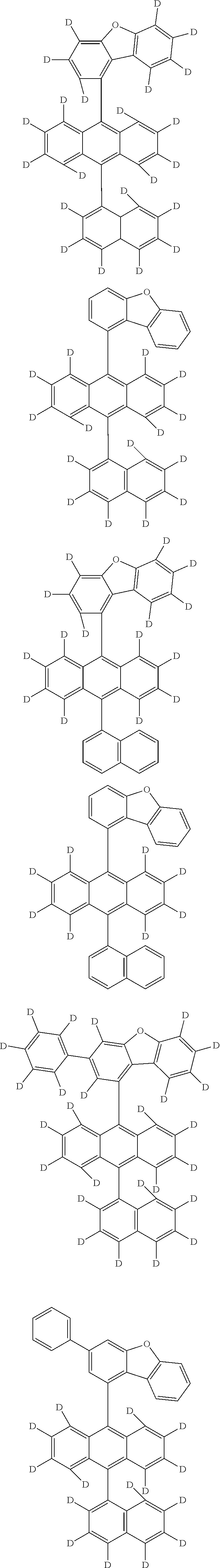

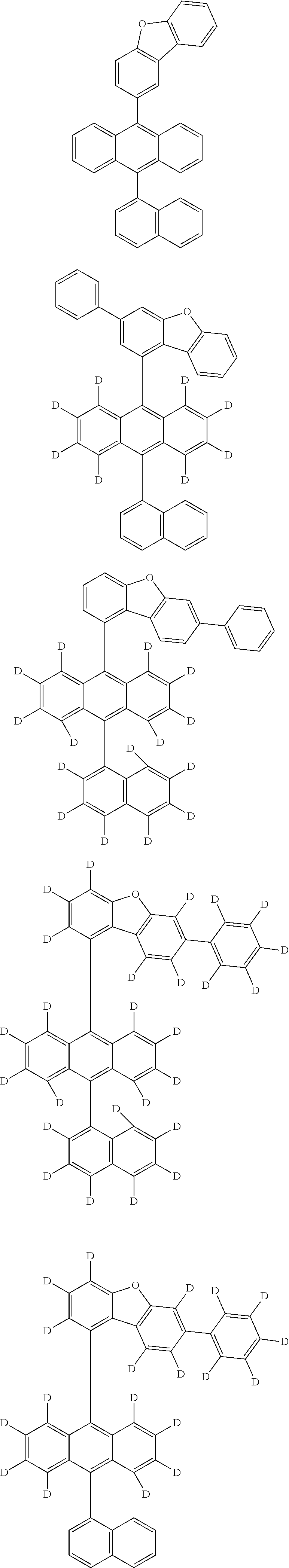

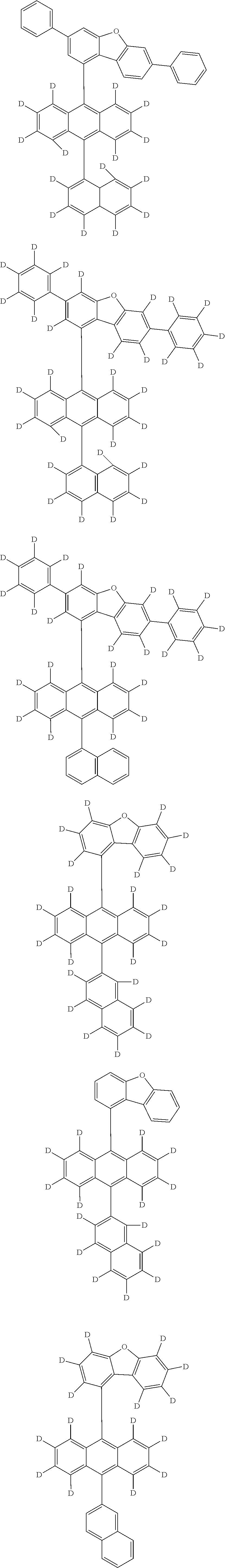

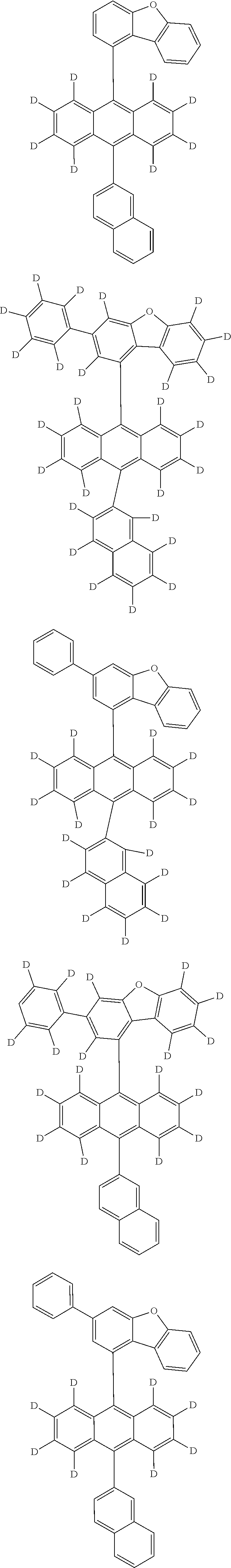

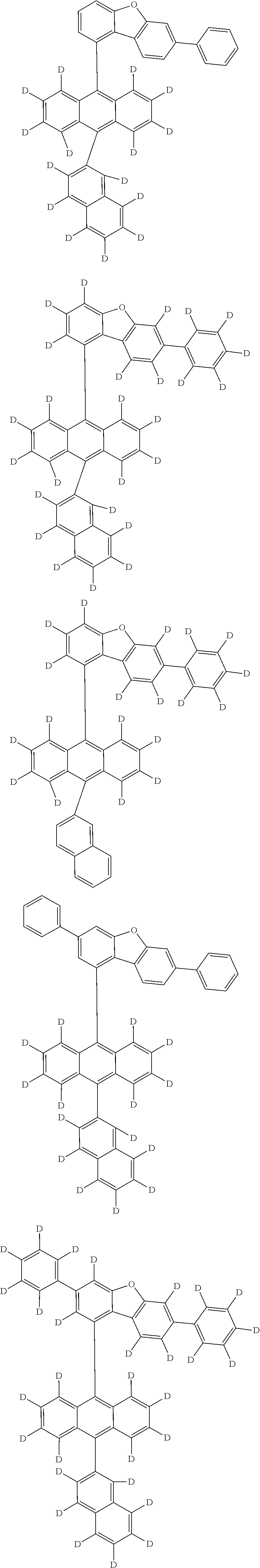

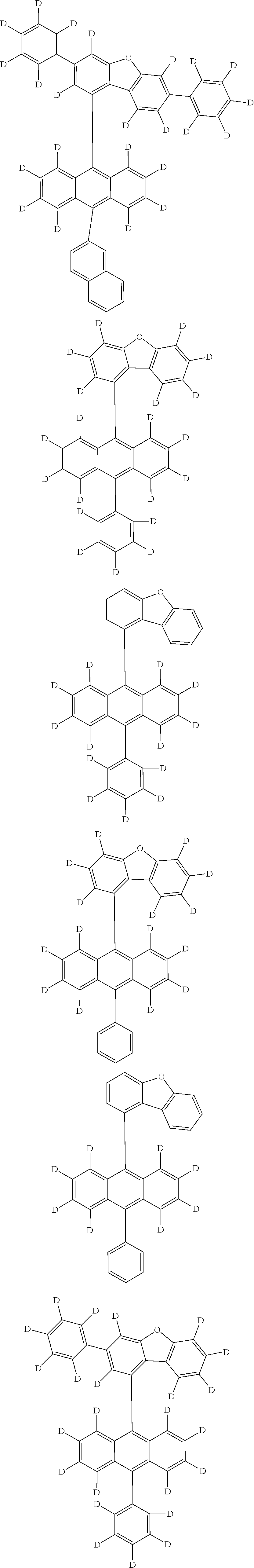

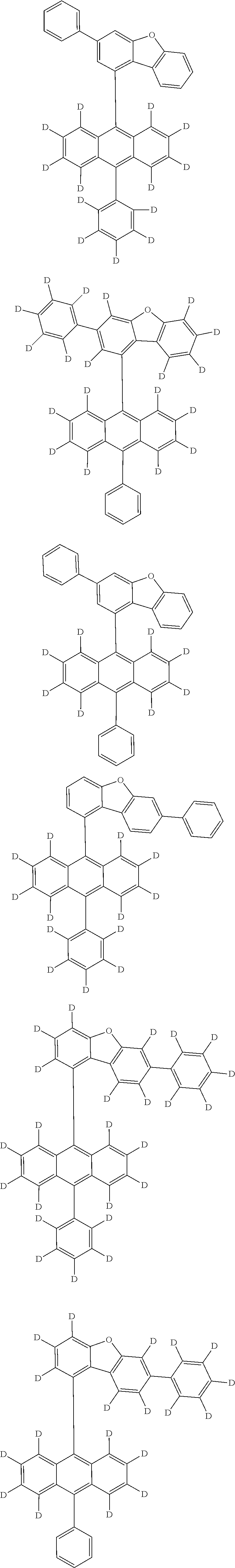

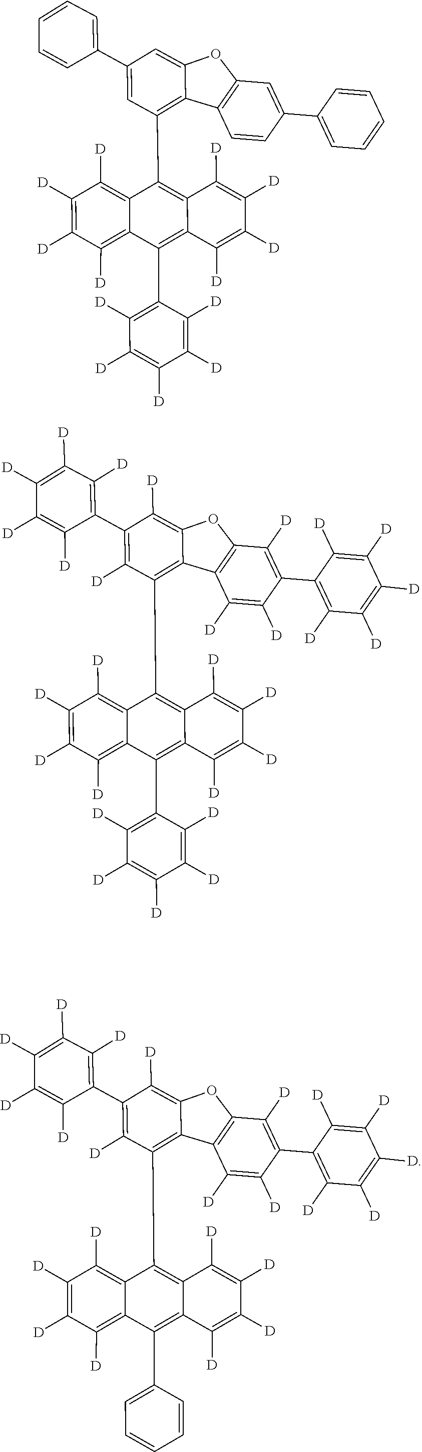

In one embodiment of the present specification, the light emitting layer includes the polycyclic compound of Chemical Formula 1 as a dopant of the light emitting layer, and includes the compound of Chemical Formula H as a host of the light emitting layer.

In one embodiment of the present specification, the light emitting layer includes a host and a dopant, and includes the host and the dopant in a weight ratio of 99:1 to 1:99, preferably in a weight ratio of 99:1 to 70:30, and more preferably in a weight ratio of 99:1 to 90:10.

According to one embodiment of the present specification, the organic material layer includes a light emitting layer, the light emitting layer includes one or more types of hosts.

According to one embodiment of the present specification, the organic material layer includes a light emitting layer, and the light emitting layer includes two or more types of mixed hosts.

According to one embodiment of the present specification, one or more of the two or more types of mixed hosts are the compound of Chemical Formula H.

According to one embodiment of the present specification, the organic material layer includes a light emitting layer, the light emitting layer includes a first host of Chemical Formula H; and a second host of Chemical Formula H, and the first host and the second host are different from each other.

According to one embodiment of the present specification, the first host:the second host are included in a weight ratio of 95:5 to 5:95, and preferably in a weight ratio of 70:30 to 30:70.

In one embodiment of the present specification, the first electrode is an anode, and the second electrode is a cathode.

According to another embodiment, the first electrode is a cathode, and the second electrode is an anode.

The organic light emitting device of the present disclosure can have structures as in the following (1) to (18), however, the structure is not limited thereto.

(1) an anode/a hole transfer layer/a light emitting layer/a cathode

(2) an anode/a hole injection layer/a hole transfer layer/a light emitting layer/a cathode

(3) an anode/a hole injection layer/a hole buffer layer/a hole transfer layer/a light emitting layer/a cathode

(4) an anode/a hole transfer layer/a light emitting layer/an electron transfer layer/a cathode

(5) an anode/a hole transfer layer/a light emitting layer/an electron transfer layer/an electron injection layer/a cathode

(6) an anode/a hole injection layer/a hole transfer layer/a light emitting layer/an electron transfer layer/a cathode

(7) an anode/a hole injection layer/a hole transfer layer/a light emitting layer/an electron transfer layer/an electron injection layer/a cathode

(8) an anode/a hole injection layer/a hole buffer layer/a hole transfer layer/a light emitting layer/an electron transfer layer/a cathode

(9) an anode/a hole injection layer/a hole buffer layer/a hole transfer layer/a light emitting layer/an electron transfer layer/an electron injection layer/a cathode

(10) an anode/a hole transfer layer/an electron blocking layer/a light emitting layer/an electron transfer layer/a cathode

(11) an anode/a hole transfer layer/an electron blocking layer/a light emitting layer/an electron transfer layer/an electron injection layer/a cathode

(12) an anode/a hole injection layer/a hole transfer layer/an electron blocking layer/a light emitting layer/an electron transfer layer/a cathode

(13) an anode/a hole injection layer/a hole transfer layer/an electron blocking layer/a light emitting layer/an electron transfer layer/an electron injection layer/a cathode

(14) an anode/a hole transfer layer/a light emitting layer/a hole blocking layer/an electron transfer layer/a cathode

(15) an anode/a hole transfer layer/a light emitting layer/a hole blocking layer/an electron transfer layer/an electron injection layer/a cathode

(16) an anode/a hole injection layer/a hole transfer layer/a light emitting layer/a hole blocking layer/an electron transfer layer/a cathode

(17) an anode/a hole injection layer/a hole transfer layer/a light emitting layer/a hole blocking layer/an electron transfer layer/an electron injection layer/a cathode

(18) an anode/a hole injection layer/a hole transfer layer/an electron blocking layer/a light emitting layer/a hole blocking layer/an electron injection and transfer layer/a cathode

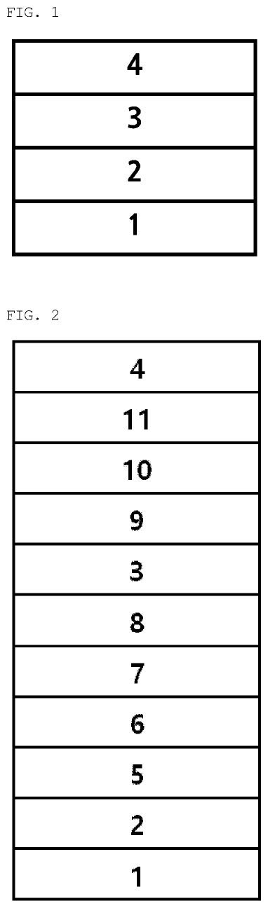

The organic light emitting device of the present disclosure can have structures as illustrated in FIG. 1 and FIG. 2, however, the structure is not limited thereto.

FIG. 1 illustrates a structure of the organic light emitting device in which a light emitting layer (3) and a cathode (4) are consecutively laminated on a substrate (1) and an anode (2). In such a structure, the polycyclic compound of Chemical Formula 1 can be included in the light emitting layer (3).

FIG. 2 illustrates a structure of the organic light emitting device in which a first hole injection layer (5), a second hole injection layer (6), a hole transfer layer (7), an electron blocking layer (8), a light emitting layer (3), a first electron transfer layer (9), a second electron transfer layer (10), an electron injection layer (11) and a cathode (4) are consecutively laminated on a substrate (1) and an anode (2). In such a structure, the polycyclic compound of Chemical Formula 1 can be included in the light emitting layer (3).

For example, the organic light emitting device according to the present disclosure can be manufactured by forming an anode on a substrate by depositing a metal, a metal oxide having conductivity, or an alloy thereof using a physical vapor deposition (PVD) method such as sputtering or e-beam evaporation, forming an organic material layer including one or more layers selected from the group consisting of a hole injection layer, a hole transfer layer, a layer carrying out hole transfer and hole injection at the same time, a light emitting layer, an electron transfer layer, an electron injection layer, and a layer carrying out electron transfer and electron injection at the same time, and then depositing a material usable as a cathode thereon. In addition to such a method, the organic light emitting device can also be manufactured by consecutively depositing a cathode material, an organic material layer and an anode material on a substrate.

The organic material layer can have a multilayer structure including a hole injection layer, a hole transfer layer, a light emitting layer, an electron transfer layer and the like, but is not limited thereto, and can have a single layer structure. In addition, using various polymer materials, the organic material layer can be prepared to a smaller number of layers using a solvent process instead of a deposition method, for example, spin coating, dip coating, doctor blading, screen printing, inkjet printing, a thermal transfer method or the like.

The anode is an electrode that injects holes, and as the anode material, materials having large work function are normally preferred so that hole injection to an organic material layer is smooth. Specific examples of the anode material usable in the present disclosure include metals such as vanadium, chromium, copper, zinc and gold, or alloys thereof; metal oxides such as zinc oxide, indium oxide, indium tin oxide (ITO) and indium zinc oxide (IZO); combinations of metals and oxides such as ZnO:Al or SnO₂:Sb; conductive polymers such as poly(3-methylthiophene), poly[3,4-(ethylene-1,2-dioxy)thiophene] (PEDOT), polypyrrole and polyaniline, but are not limited thereto.

The cathode is an electrode that injects electrons, and as the cathode material, materials having small work function are normally preferred so that electron injection to an organic material layer is smooth. Specific examples of the cathode material include metals such as magnesium, calcium, sodium, potassium, titanium, indium, yttrium, lithium, gadolinium, aluminum, silver, tin and lead, or alloys thereof; multilayer structure materials such as LiF/Al or LiO₂/Al, and the like, but are not limited thereto.

The hole injection layer is a layer performing a role of smoothly injecting holes from an anode to a light emitting layer, and can have a single layer or multilayer structure. The hole injection material is a material capable of favorably receiving holes from an anode at a low voltage, and the highest occupied molecular orbital (HOMO) of the hole injection material is preferably in between the work function of the anode material and the HOMO of surrounding organic material layers. Specific examples of the hole injection material include metal porphyrins, oligothiophene, arylamine-based organic materials, hexanitrile hexaazatriphenylene-based organic materials, quinacridone-based organic materials, perylene-based organic materials, anthraquinone, and polyaniline- and polythiophene-based conductive polymers, and the like, but are not limited thereto. The hole injection layer can have a thickness of 1 nm to 150 nm. The hole injection layer having a thickness of 1 nm or greater has an advantage of preventing hole injection properties from declining, and the thickness being 150 nm or less has an advantage of preventing a driving voltage from increasing to enhance hole migration caused by the hole injection layer being too thick. In one embodiment of the present specification, the hole injection layer has a multilayer structure of two or more layers.

The hole transfer layer can perform a role of smoothly transferring holes. As the hole transfer material, materials capable of receiving holes from an anode or a hole injection layer, moving the holes to a light emitting layer, and having high mobility for the holes are suited. Specific examples thereof include arylamine-based organic materials, conductive polymers, block copolymers having conjugated parts and non-conjugated parts together, and the like, but are not limited thereto.

A hole buffer layer can be further provided between the hole injection layer and the hole transfer layer, and can include hole injection or transfer materials known in the art.

An electron blocking layer can be provided between the hole transfer layer and the light emitting layer. As the electron blocking layer, the spiro compound described above, or materials known in the art can be used.

The light emitting layer can emit red, green or blue, and can be formed with a phosphorescent material or a fluorescent material. The light emitting material is a material capable of emitting light in a visible region by receiving holes and electrons from a hole transfer layer and an electron transfer layer, respectively, and binding the holes and the electrons, and is preferably a material having favorable quantum efficiency for fluorescence or phosphorescence. Specific examples thereof include 8-hydroxy-quinoline aluminum complexes (Alq₃); carbazole-based compounds; dimerized styryl compounds; BAlq; 10-hydroxybenzoquinoline-metal compounds; benzoxazole-, benzothiazole- and benzimidazole-based compounds; poly(p-phenylenevinylene) (PPV)-based polymers; spiro compounds; polyfluorene, rubrene, and the like, but are not limited thereto.

As the host material of the light emitting layer, fused aromatic ring derivatives, heteroring-containing compounds or the like can be included. Specifically, anthracene derivatives, pyrene derivatives, naphthalene derivatives, pentacene derivatives, phenanthrene compounds, fluoranthene compounds or the like can be included as the fused aromatic ring derivative, and carbazole derivatives, dibenzofuran derivatives, ladder-type furan compounds, pyrimidine derivatives or the like can be included as the heteroring-containing compound, however, the host material is not limited thereto.

When the light emitting layer emits red light, phosphorescent materials such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr) or octaethylporphyrin platinum (PtOEP), or fluorescent materials such as tris(8-hydroxyquinolino)aluminum (Alq₃) can be used as the light emitting dopant, however, the light emitting dopant is not limited thereto. When the light emitting layer emits green light, phosphorescent materials such as fac tris(2-phenylpyridine)iridium (Ir(ppy)₃), or fluorescent materials such as tris(8-hydroxyquinolino)aluminum (Alq₃) can be used as the light emitting dopant, however, the light emitting dopant is not limited thereto. When the light emitting layer emits blue light, phosphorescent materials such as (4,6-F2ppy)₂Irpic, or fluorescent materials such as spiro-DPVBi, spiro-6P, distyrylbenzene (DSB), distyrylarylene (DSA), PFO-based polymers or PPV-based polymers can be used as the light emitting dopant, however, the light emitting dopant is not limited thereto.

A hole blocking layer can be provided between the electron transfer layer and the light emitting layer, and materials known in the art can be used.

The electron transfer layer can perform a role of smoothly transferring electrons, and can have a single layer or multilayer structure. As the electron transfer material, materials capable of favorably receiving electrons from a cathode, moving the electrons to a light emitting layer, and having high mobility for the electrons are suited. Specific examples thereof include Al complexes of 8-hydroxyquinoline; complexes including Alq₃; organic radical compounds; hydroxyflavon-metal complexes, and the like, but are not limited thereto. The electron transfer layer can have a thickness of 1 nm to 50 nm. The electron transfer layer having a thickness of 1 nm or greater has an advantage of preventing electron transfer properties from declining, and the thickness being 50 nm or less has an advantage of preventing a driving voltage from increasing to enhance electron migration caused by the electron transfer layer being too thick. In one embodiment of the present specification, the electron transfer layer has a multilayer structure of two or more layers, and the electron transfer layer adjacent to the cathode includes an n-type dopant.

The electron injection layer can perform a role of smoothly injecting electrons. As the electron injection material, compounds having an electron transferring ability, having an electron injection effect from a cathode, having an excellent electron injection effect for a light emitting layer or light emitting material, and preventing excitons generated in the light emitting layer from moving to a hole injection layer, and in addition thereto, having an excellent thin film forming ability are preferred. Specific examples thereof can include fluorenone, anthraquinodimethane, diphenoquinone, thiopyran dioxide, oxazole, oxadiazole, triazole, imidazole, perylene tetracarboxylic acid, fluorenylidene methane, anthrone or the like, and derivatives thereof, metal complex compounds, nitrogen-containing 5-membered ring derivatives, and the like, but are not limited thereto.

The metal complex compound includes 8-hydroxyquinolinato lithium, bis(8-hydroxyquinolinato)zinc, bis(8-hydroxy-quinolinato)copper, bis(8-hydroxyquinolinato)manganese, tris(8-hydroxyquinolinato)aluminum, tris(2-methyl-8-hydroxy-quinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)-chloro-gallium, bis(2-methyl-8-quinolinato)(o-cresolato)gallium, bis(2-methyl-8-quinolinato)(1-naphtholato)aluminum, bis(2-methyl-8-quinolinato)-(2-naphtholato)gallium and the like, but is not limited thereto.

The hole blocking layer is a layer blocking holes from reaching a cathode, and can be generally formed under the same condition as the hole injection layer. Specific examples thereof can include oxadiazole derivatives, triazole derivatives, phenanthroline derivatives, BCP, aluminum complexes and the like, but are not limited thereto.

The organic light emitting device according to the present disclosure can be a top-emission type, a bottom-emission type or a dual-emission type depending on the materials used.

### EXAMPLES

Hereinafter, the present specification will be described in detail with reference to examples, comparative examples and the like. However, the examples and the comparative examples according to the present specification can be modified to various other forms, and the scope of the present specification is not to be construed as being limited to the examples and the comparative examples described below. The examples and the comparative examples of the present specification are provided in order to more fully describe the present specification to those having average knowledge in the art.

### Synthesis Example 1. Synthesis of Compound M1

### 1) Synthesis of Int1

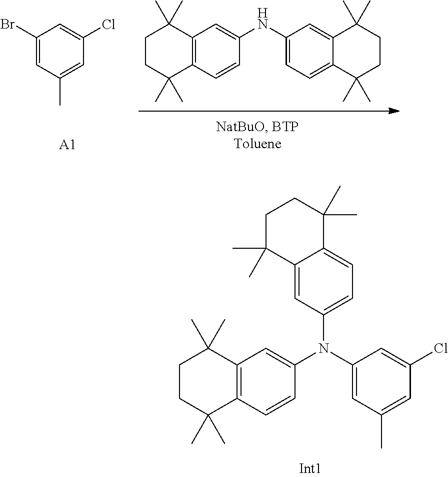

After introducing 1-bromo-3-chloro-5-methylbenzene (30 g), bis(5,5,8,8-tetramethyl-5,6,7,8-tetrahydronaphthalen-2-yl)amine (56.9 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int1 (55 g, yield 73%). MS[M+H]+=515

### 2) Synthesis of Int2

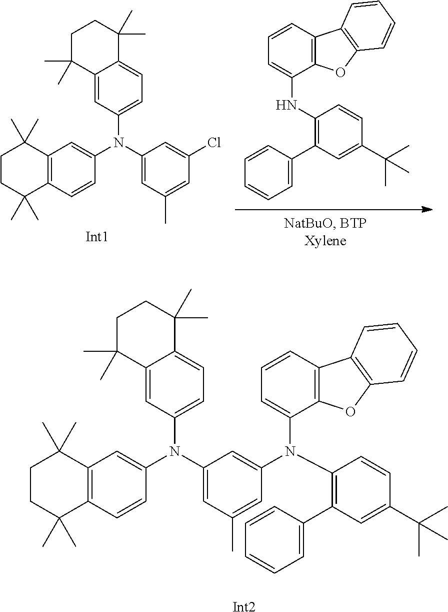

After introducing Int1 (30 g), N-(5-(tert-butyl)-[1,1′-biphenyl]-2-yl)dibenzo[b,d]furan-4-amine (22.8 g), sodium-tert-butoxide (16.8 g) and bis(tri-tert-butylphosphine)-palladium(0) (0.6 g) to xylene (600 ml), the mixture was refluxed for 6 hours. After the reaction was finished, the result was extracted and then recrystallized to obtain Int2 (36 g, yield 71%). MS[M+H]+=870

### 3) Synthesis of Compound M1

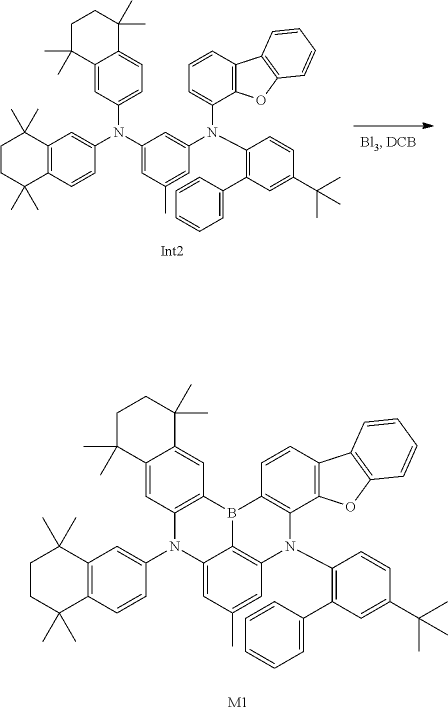 [SMILES: Cc1cc(N(c2ccc3c(c2)C(C)(C)CCC3(C)C)c2ccc3c(c2)C(C)(C)CCC3(C)C)cc(N(c2ccc(C(C)(C)C)cc2-c2ccccc2)c2cccc3c2oc2ccccc23)c1 ; Cc1cc2c3c(c1)N(c1ccc(C(C)(C)C)cc1-c1ccccc1)c1c(ccc4c1oc1ccccc14)B3c1cc3c(cc1N2c1ccc2c(c1)C(C)(C)CCC2(C)C)C(C)(C)CCC3(C)C ; "M1"]

After introducing Int2 (25 g) and boron triiodide (19.2 g) to 1,2-dichlorobenzene (250 ml) under a nitrogen atmosphere, the mixture was stirred for 8 hours at 160° C. After the reaction was finished, the result was extracted and then recrystallized to obtain Compound M1 (7.7 g, yield 31%). MS[M+H]+=878

### Synthesis Example 2. Synthesis of Compound M2

### 1) Synthesis of Int3

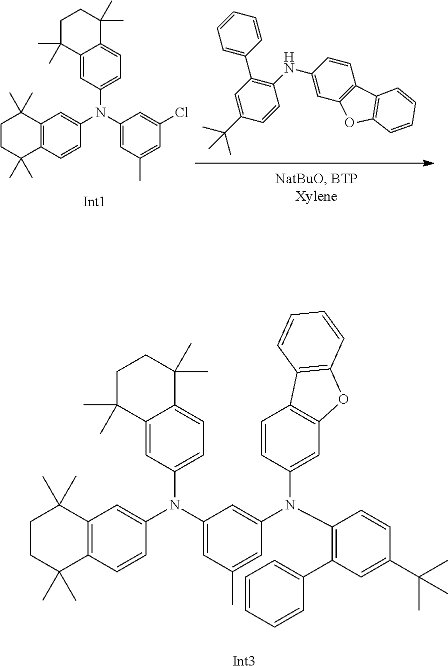

After introducing Int1 (30 g), N-(5-(tert-butyl)-[1,1′-biphenyl]-2-yl)dibenzo[b,d]furan-3-amine (22.8 g), sodium-tert-butoxide (16.8 g) and bis(tri-tert-butylphosphine)-palladium(0) (0.6 g) to xylene (600 ml), the mixture was refluxed for 6 hours. After the reaction was finished, the result was extracted and then recrystallized to obtain Int3 (38 g, yield 75%). MS[M+H]+=870

### 2) Synthesis of Compound M2

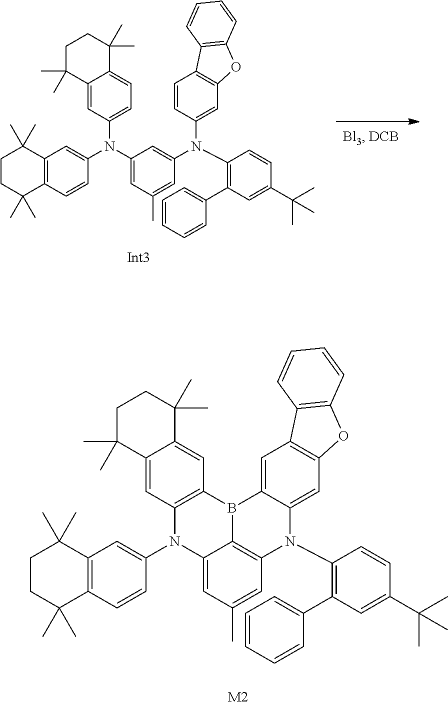 [SMILES: Cc1cc(N(c2ccc3c(c2)C(C)(C)CCC3(C)C)c2ccc3c(c2)C(C)(C)CCC3(C)C)cc(N(c2ccc3c(c2)oc2ccccc23)c2ccc(C(C)(C)C)cc2-c2ccccc2)c1 ; Cc1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)CCC2(C)C)C(C)(C)CCC3(C)C ; "M2"]

After introducing Int3 (25 g) and boron triiodide (19.2 g) to 1,2-dichlorobenzene (250 ml) under a nitrogen atmosphere, the mixture was stirred for 8 hours at 160° C. After the reaction was finished, the result was extracted and then recrystallized to obtain Compound M2 (8 g, yield 32%). MS[M+H]+=878

### Synthesis Example 3. Synthesis of Compound M3

### 1) Synthesis of Compound M3

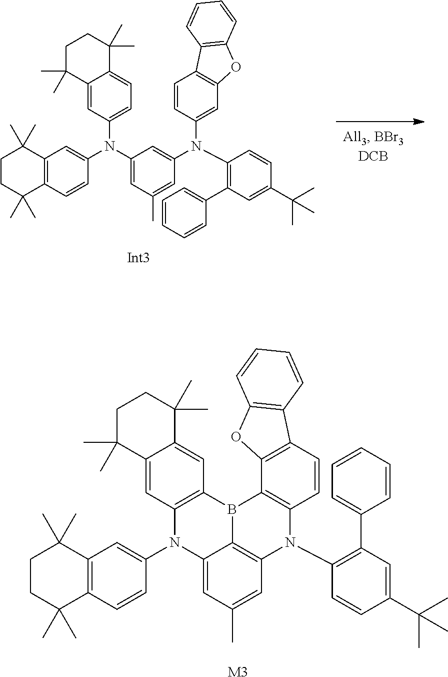

After introducing Int3 (25 g), aluminum iodide (4.7 g) and boron tribromide (21.8 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M3 (7.3 g, yield 29%). MS[M+H]+=878

### Synthesis Example 4. Synthesis of Compound M4

### 1) Synthesis of Int4

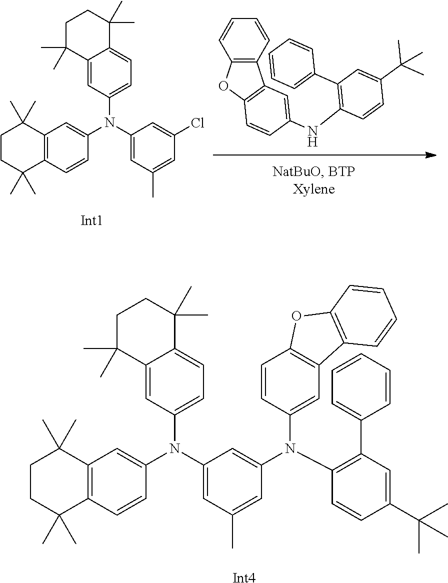

After introducing Int1 (30 g), N-(5-(tert-butyl)-[1,1′-biphenyl]-2-yl)dibenzo[b,d]furan-2-amine (22.8 g), sodium-tert-butoxide (16.8 g) and bis(tri-tert-butylphosphine)-palladium(0) (0.6 g) to xylene (600 ml), the mixture was refluxed for 6 hours. After the reaction was finished, the result was extracted and then recrystallized to obtain Int4 (39 g, yield 77%). MS[M+H]+=870

### 2) Synthesis of Compound M4

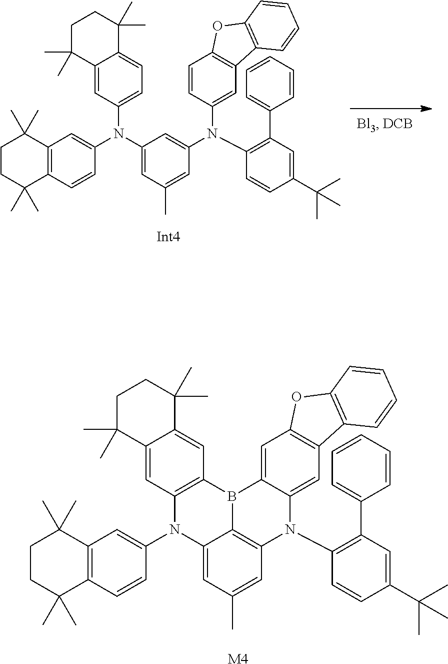

After introducing Int4 (25 g) and boron triiodide (19.2 g) to 1,2-dichlorobenzene (250 ml) under a nitrogen atmosphere, the mixture was stirred for 8 hours at 160° C. After the reaction was finished, the result was extracted and then recrystallized to obtain Compound M4 (7.6 g, yield 30%). MS[M+H]+=878

### Synthesis Example 5. Synthesis of Compound M5

### 1) Synthesis of Int5

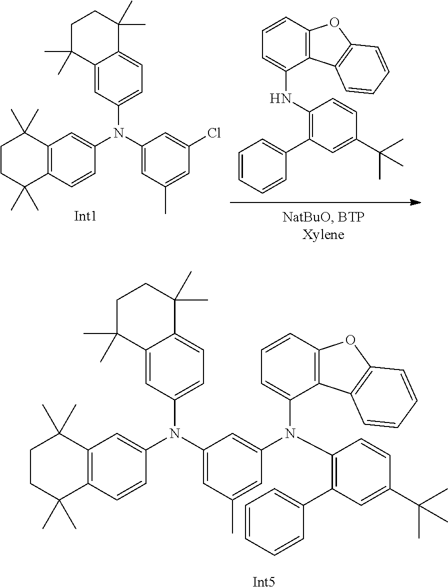

After introducing Int1 (30 g), N-(5-(tert-butyl)-[1,1′-biphenyl]-2-yl)dibenzo[b,d]furan-1-amine (22.8 g), sodium-tert-butoxide (16.8 g) and bis(tri-tert-butylphosphine)-palladium(0) (0.6 g) to xylene (600 ml), the mixture was refluxed for 6 hours. After the reaction was finished, the result was extracted and then recrystallized to obtain Int5 (36 g, yield 71%). MS[M+H]+=870

### 2) Synthesis of Compound M5

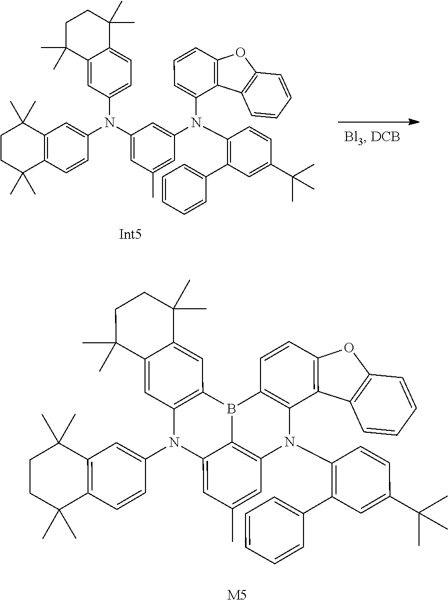 [SMILES: Cc1cc(N(c2ccc3c(c2)C(C)(C)CCC3(C)C)c2ccc3c(c2)C(C)(C)CCC3(C)C)cc(N(c2ccc(C(C)(C)C)cc2-c2ccccc2)c2cccc3oc4ccccc4c23)c1 ; Cc1cc2c3c(c1)N(c1ccc(C(C)(C)C)cc1-c1ccccc1)c1c(ccc4oc5ccccc5c14)B3c1cc3c(cc1N2c1ccc2c(c1)C(C)(C)CCC2(C)C)C(C)(C)CCC3(C)C ; "M5"]

After introducing Int5 (25 g) and boron triiodide (19.2 g) to 1,2-dichlorobenzene (250 ml) under a nitrogen atmosphere, the mixture was stirred for 8 hours at 160° C. After the reaction was finished, the result was extracted and then recrystallized to obtain Compound M5 (7.9 g, yield 31%). MS[M+H]+=878

### Synthesis Example 6. Synthesis of Compound M6

### 1) Synthesis of Int6

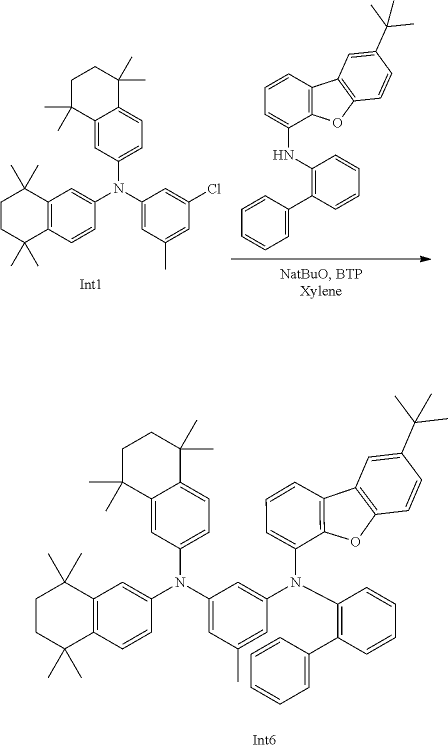

After introducing Int1 (30 g), N-([1,1′-biphenyl]-2-yl)-8-(tert-butyl)dibenzo[b,d]furan-4-amine (22.8 g), sodium-tert-butoxide (16.8 g) and bis(tri-tert-butylphosphine)-palladium(0) (0.6 g) to xylene (600 ml), the mixture was refluxed for 6 hours. After the reaction was finished, the result was extracted and then recrystallized to obtain Int6 (38 g, yield 75%). MS[M+H]+=870

### 2) Synthesis of Compound M6

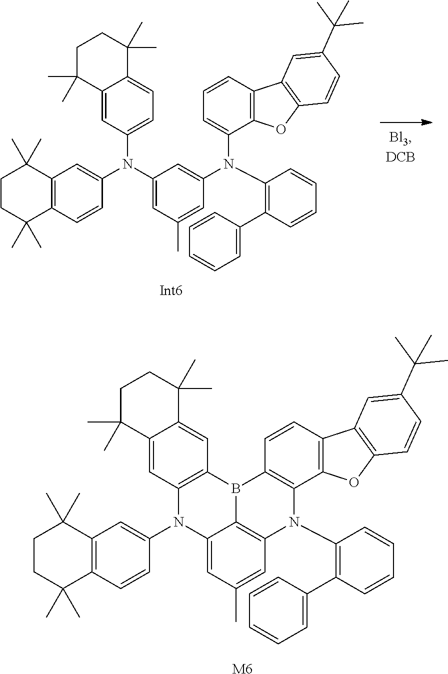

After introducing Int6 (25 g) and boron triiodide (19.2 g) to 1,2-dichlorobenzene (250 ml) under a nitrogen atmosphere, the mixture was stirred for 8 hours at 160° C. After the reaction was finished, the result was extracted and then recrystallized to obtain Compound M6 (8.2 g, yield 33%). MS[M+H]+=878

### Synthesis Example 7. Synthesis of Compound M7

### 1) Synthesis of Int7

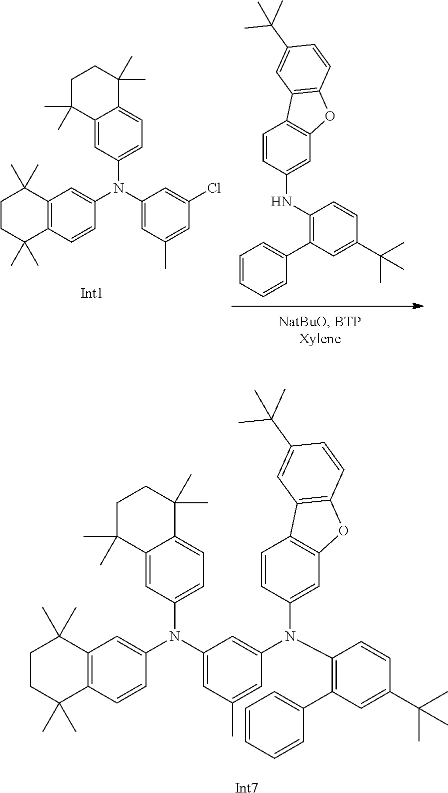 [SMILES: Cc1cc(Cl)cc(N(c2ccc3c(c2)C(C)(C)CCC3(C)C)c2ccc3c(c2)C(C)(C)CCC3(C)C)c1 ; CC(C)(C)c1ccc(Nc2ccc3c(c2)oc2ccc(C(C)(C)C)cc23)c(-c2ccccc2)c1 ; Cc1cc(N(c2ccc3c(c2)C(C)(C)CCC3(C)C)c2ccc3c(c2)C(C)(C)CCC3(C)C)cc(N(c2ccc3c(c2)oc2ccc(C(C)(C)C)cc23)c2ccc(C(C)(C)C)cc2-c2ccccc2)c1 ; "Int7"]

After introducing Int1 (30 g), 8-(tert-butyl)-N-(5-(tert-butyl)-[1,1′-biphenyl]-2-yl)dibenzo[b,d]furan-3-amine (26.1 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int7 (39 g, yield 72%). MS[M+H]+=926

### 2) Synthesis of Compound M7

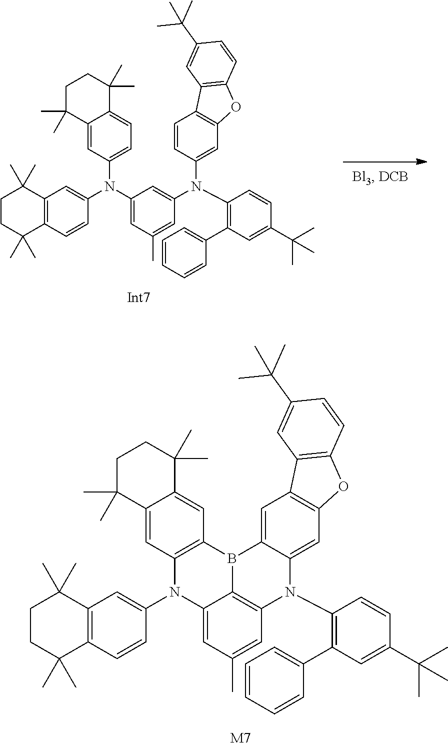

After introducing Int1 (25 g) and boron triiodide (18 g) to 1,2-dichlorobenzene (250 ml) under a nitrogen atmosphere, the mixture was stirred for 8 hours at 160° C. After the reaction was finished, the result was extracted and then recrystallized to obtain Compound M7 (8.1 g, yield 32%). MS[M+H]+=934

### Synthesis Example 8. Synthesis of Compound M8

### 1) Synthesis of Int8

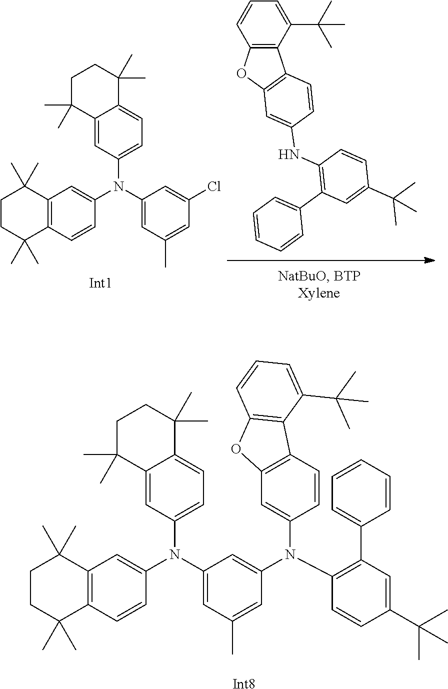

After introducing Int1 (30 g), 9-(tert-butyl)-N-(5-(tert-butyl)-[1,1′-biphenyl]-2-yl)dibenzo[b,d]furan-3-amine (26.1 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int8 (41 g, yield 76%). MS[M+H]+=926

### 2) Synthesis of Compound M8

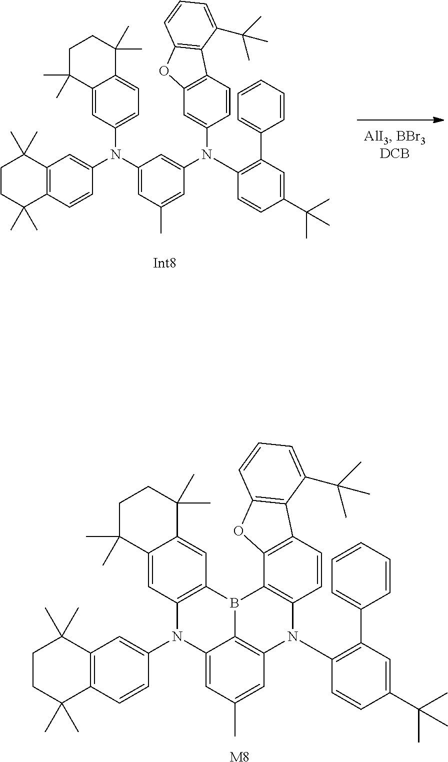

After introducing Int8 (25 g), aluminum iodide (4.4 g) and boron tribromide (20.5 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M8 (8.2 g, yield 33%). MS[M+H]+=934

### Synthesis Example 9. Synthesis of Compound M9

### 1) Synthesis of Int9

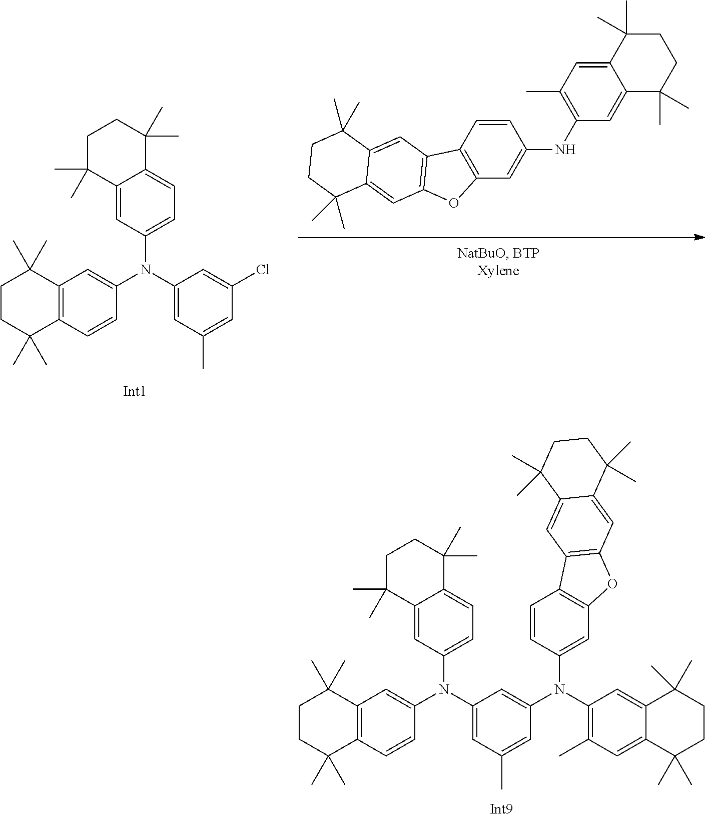

After introducing Int1 (30 g), 7,7,10,10-tetramethyl-N-(3,5,5,8,8-pentamethyl-5,6,7,8-tetrahydro-naphthalen-2-yl)-7,8,9,10-tetrahydronaphtho[2,3-b]benzofuran-3-amine (28.8 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int9 (40 g, yield 71%). MS[M+H]+=972

### 2) Synthesis of Compound M9

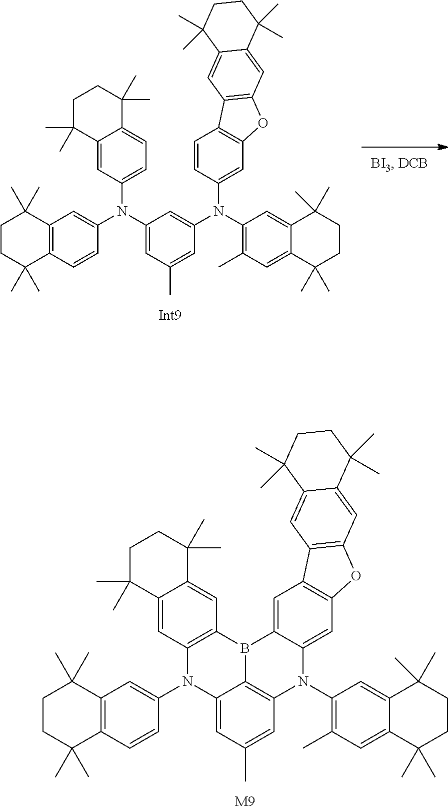

After introducing Int9 (25 g) and boron triiodide (17.2 g) to 1,2-dichlorobenzene (250 ml) under a nitrogen atmosphere, the mixture was stirred for 8 hours at 160° C. After the reaction was finished, the result was extracted and then recrystallized to obtain Compound M9 (7.9 g, yield 31%). MS[M+H]+=980

### Synthesis Example 10. Synthesis of Compound M10

### 1) Synthesis of Int10

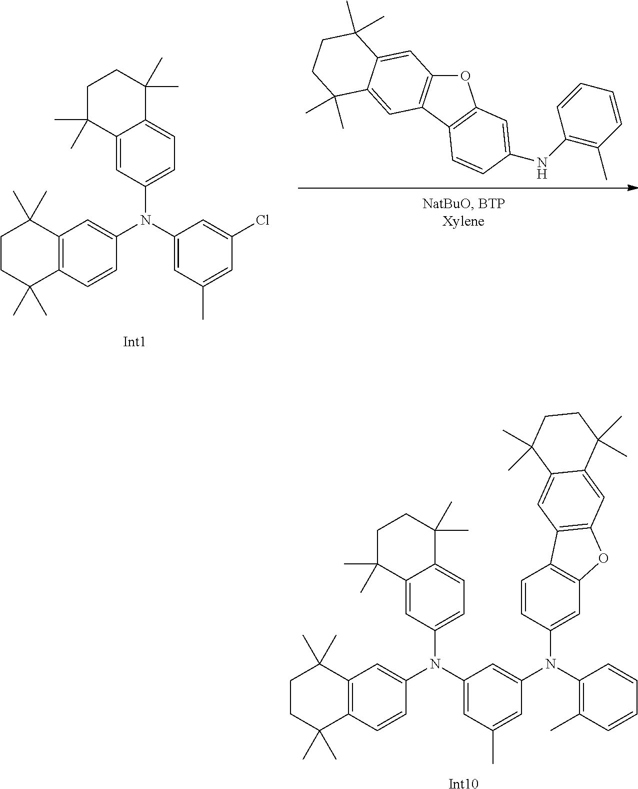

After introducing Int1 (30 g), 7,7,10,10-tetramethyl-N-(o-tolyl)-7,8,9,10-tetrahydronaphtho[2,3-b]-benzofuran-3-amine (22.3 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int10 (39 g, yield 78%). MS[M+H]+=862

### 2) Synthesis of Compound M10

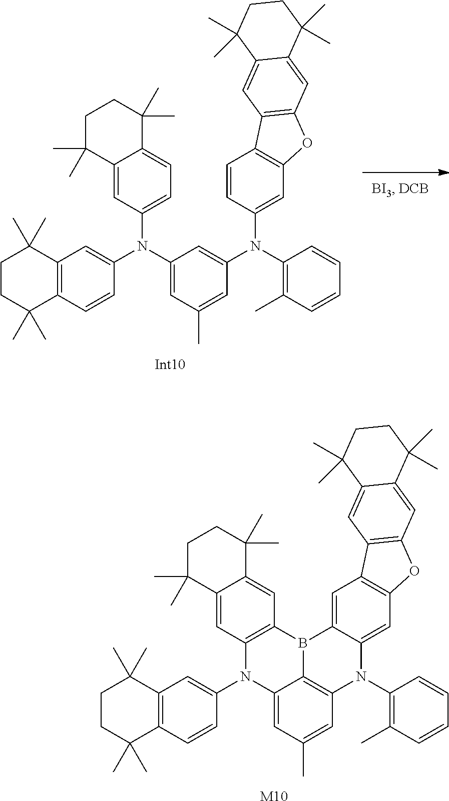

After introducing Int10 (25 g) and boron triiodide (19.3 g) to 1,2-dichlorobenzene (250 ml) under a nitrogen atmosphere, the mixture was stirred for 8 hours at 160° C. After the reaction was finished, the result was extracted and then recrystallized to obtain Compound M10 (7.8 g, yield 31%). MS[M+H]+=870

### Synthesis Example 11. Synthesis of Compound M11

### 1) Synthesis of Int11

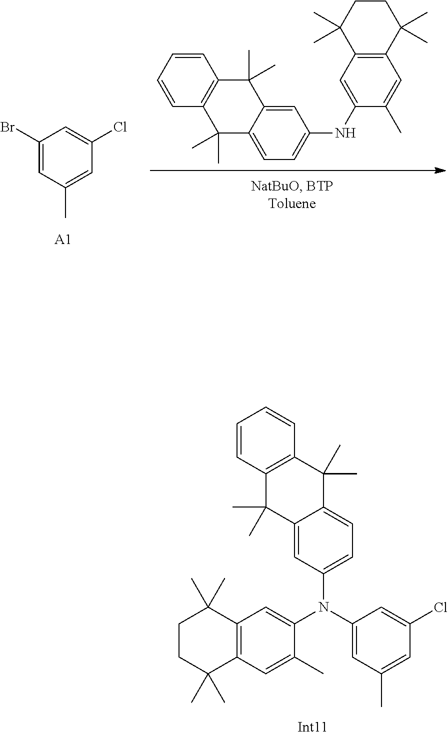

After introducing 1-bromo-3-chloro-5-methylbenzene (30 g), 9,9,10,10-tetramethyl-N-(3,5,5,8,8-pentamethyl-5,6,7,8-tetrahydronaphthalen-2-yl)-9,10-dihydro-anthracen-2-amine (66 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int11 (61 g, yield 73%). MS[M+H]+=577

### 2) Synthesis of Int12

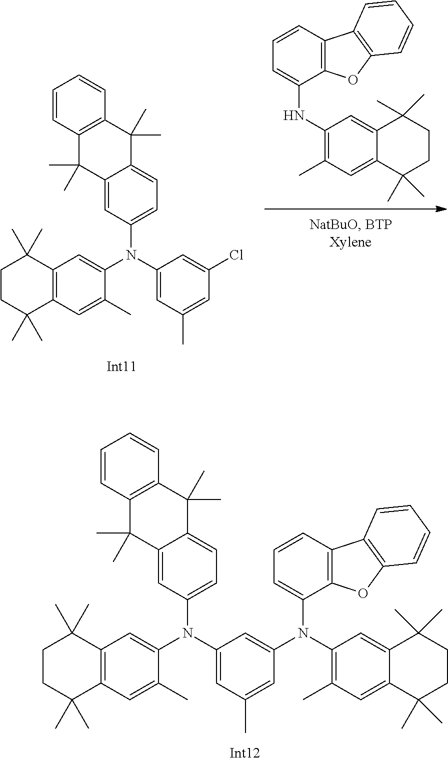

After introducing Int11 (30 g), N-(3,5,5,8,8-pentamethyl-5,6,7,8-hydronaphthalen-2-yl)dibenzo[b,d]furan-4-amine (20 g), sodium-tert-butoxide (15 g) and bis(tri-tert-butylphosphine)palladium(0) (0.5 g) to xylene (600 ml), the mixture was refluxed for 6 hours. After the reaction was finished, the result was extracted and then recrystallized to obtain Int12 (37 g, yield 77%). MS[M+H]+=924

### 3) Synthesis of Compound M11

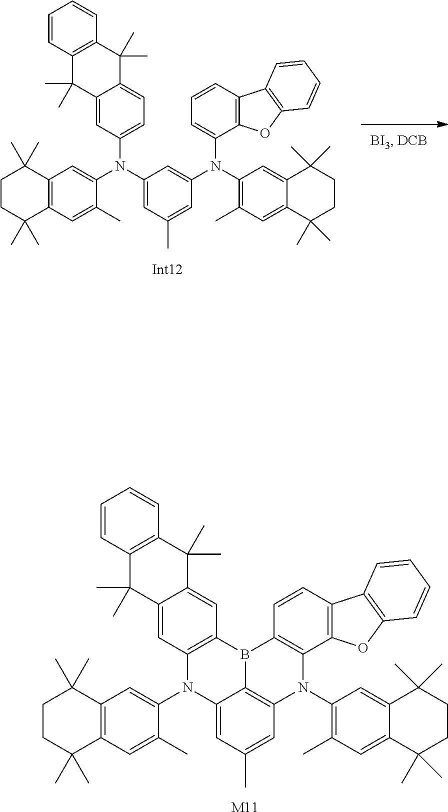

After introducing Int12 (25 g) and boron triiodide (18 g) to 1,2-dichlorobenzene (250 ml) under a nitrogen atmosphere, the mixture was stirred for 8 hours at 160° C. After the reaction was finished, the result was extracted and then recrystallized to obtain Compound M11 (7.5 g, yield 30%). MS[M+H]+=932

### Synthesis Example 12. Synthesis of Compound M12

### 1) Synthesis of Int13

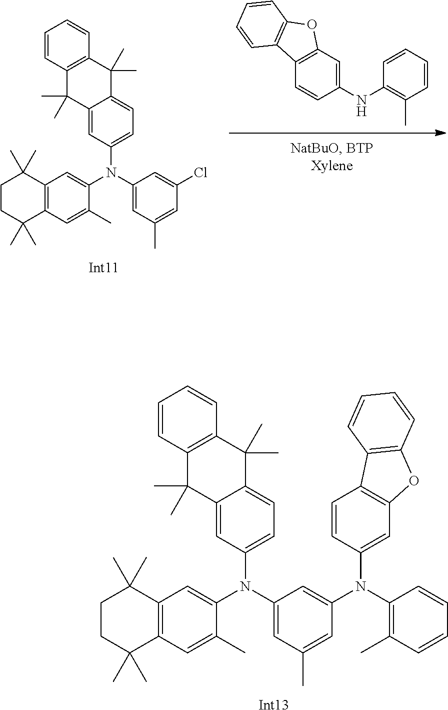

After introducing Int11 (30 g), N-(o-tolyl)-dibenzo[b,d]furan-3-amine (14.3 g), sodium-tert-butoxide (15 g) and bis(tri-tert-butylphosphine)palladium(0) (0.5 g) to xylene (600 ml), the mixture was refluxed for 6 hours. After the reaction was finished, the result was extracted and then recrystallized to obtain Int13 (33 g, yield 78%). MS[M+H]+=814

### 2) Synthesis of Compound M12

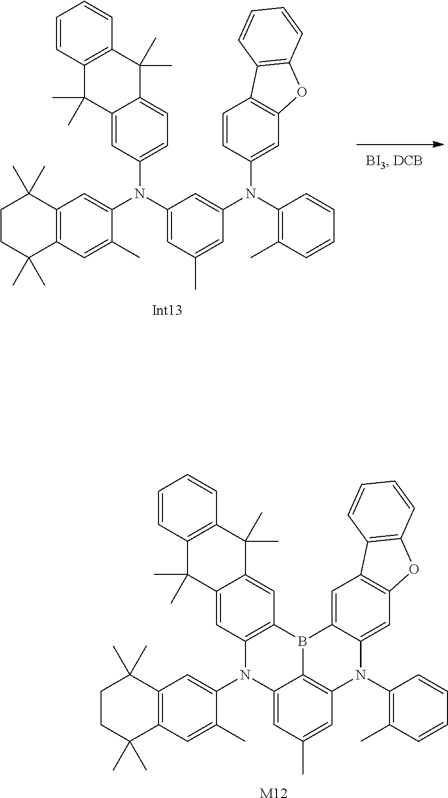

After introducing Int13 (25 g) and boron triiodide (20.4 g) to 1,2-dichlorobenzene (250 ml) under a nitrogen atmosphere, the mixture was stirred for 8 hours at 160° C. After the reaction was finished, the result was extracted and then recrystallized to obtain Compound M12 (7.5 g, yield 30%). MS[M+H]+=821

### Synthesis Example 13. Synthesis of Compound M13

### 1) Synthesis of Int14

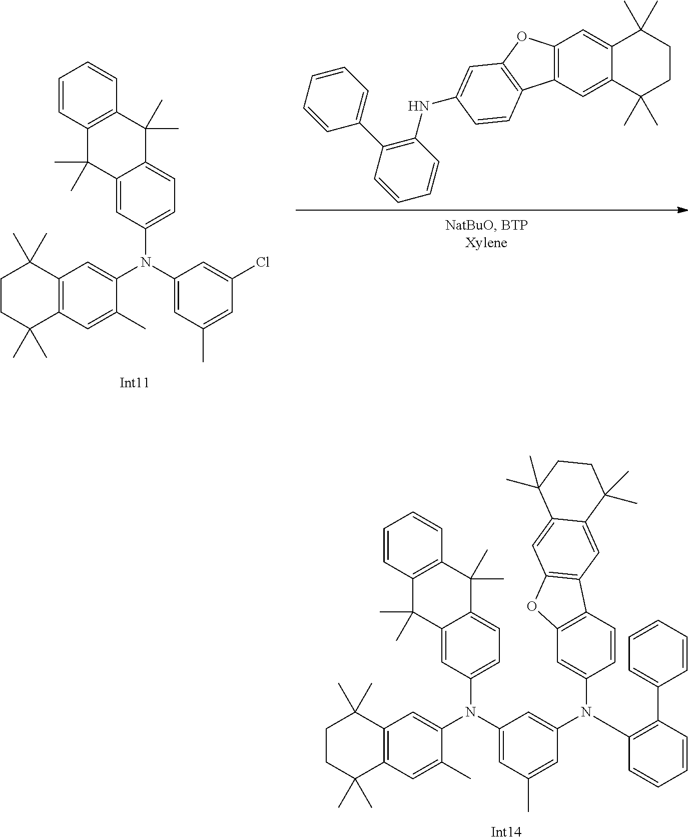

After introducing Int11 (30 g), N-([1,1′-biphenyl]-2-yl)-7,7,10,10-tetramethyl-7,8,9,10-tetrahydronaphtho-[2,3-b]benzofuran-3-amine (23.2 g), sodium-tert-butoxide (15 g) and bis(tri-tert-butylphosphine)palladium(0) (0.5 g) to xylene (600 ml), the mixture was refluxed for 6 hours. After the reaction was finished, the result was extracted and then recrystallized to obtain Int14 (38 g, yield 74%). MS[M+H]+=986

### 2) Synthesis of Compound M13

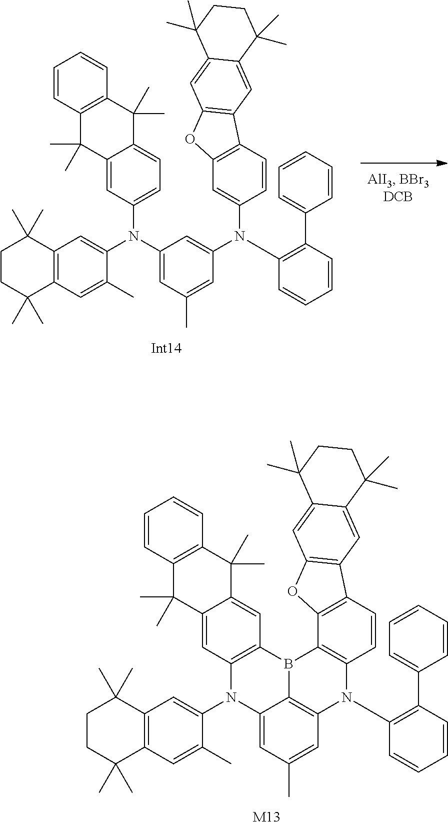

After introducing Int14 (25 g), aluminum iodide (4.1 g) and boron tribromide (19.2 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M13 (7.4 g, yield 29%). MS[M+H]+=994

### Synthesis Example 14. Synthesis of Compound M14

### 1) Synthesis of Int15

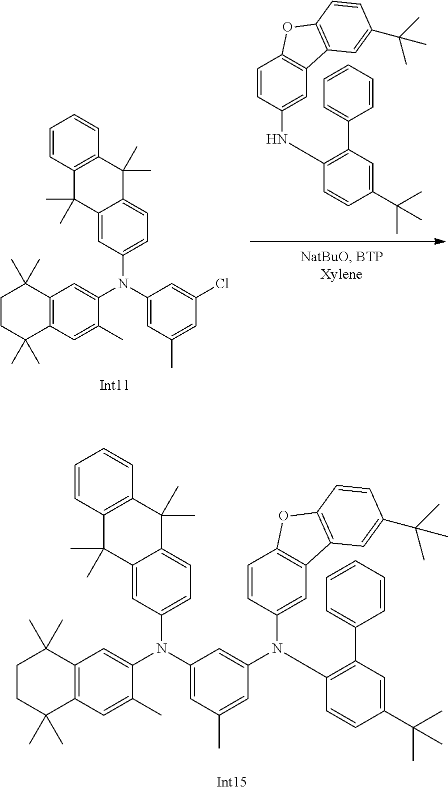

After introducing Int11 (30 g), 8-(tert-butyl)-N-(5-(tert-butyl)-[1,1′-biphenyl]-2-yl)dibenzo[b,d]furan-2-amine (23.3 g), sodium-tert-butoxide (15 g) and bis(tri-tert-butylphosphine)palladium(0) (0.5 g) to xylene (600 ml), the mixture was refluxed for 6 hours. After the reaction was finished, the result was extracted and then recrystallized to obtain Int15 (37 g, yield 73%). MS[M+H]+=988

### 2) Synthesis of Compound M14

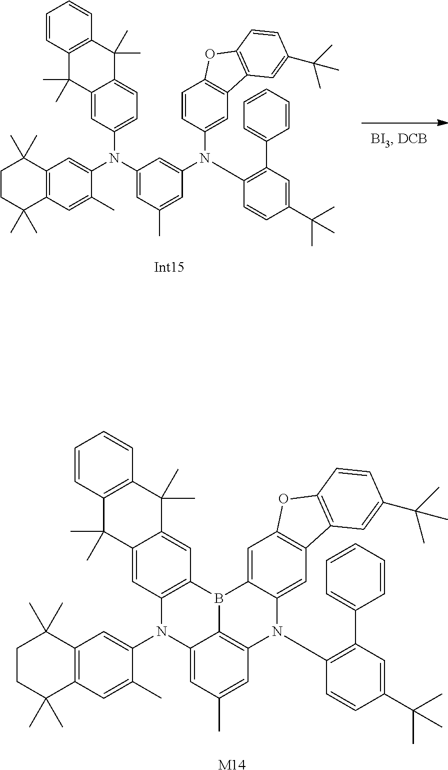

After introducing Int15 (25 g) and boron triiodide (16.8 g) to 1,2-dichlorobenzene (250 ml) under a nitrogen atmosphere, the mixture was stirred for 8 hours at 160° C. After the reaction was finished, the result was extracted and then recrystallized to obtain Compound M14 (7.6 g, yield 30%). MS[M+H]+=996

### Synthesis Example 15. Synthesis of Compound M15

### 1) Synthesis of Int16

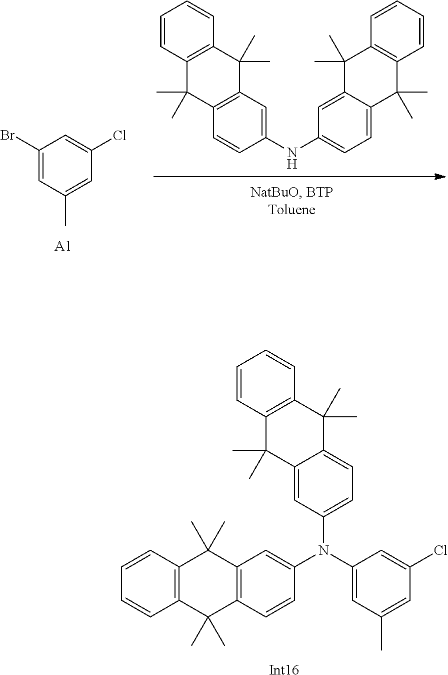

After introducing 1-bromo-3-chloro-5-methylbenzene (30 g), bis(9,9,10,10-tetramethyl-9,10-dihydroanthracen-2-yl)amine (71 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int16 (68 g, yield 76%). MS[M+H]+=611

### 2) Synthesis of Int17

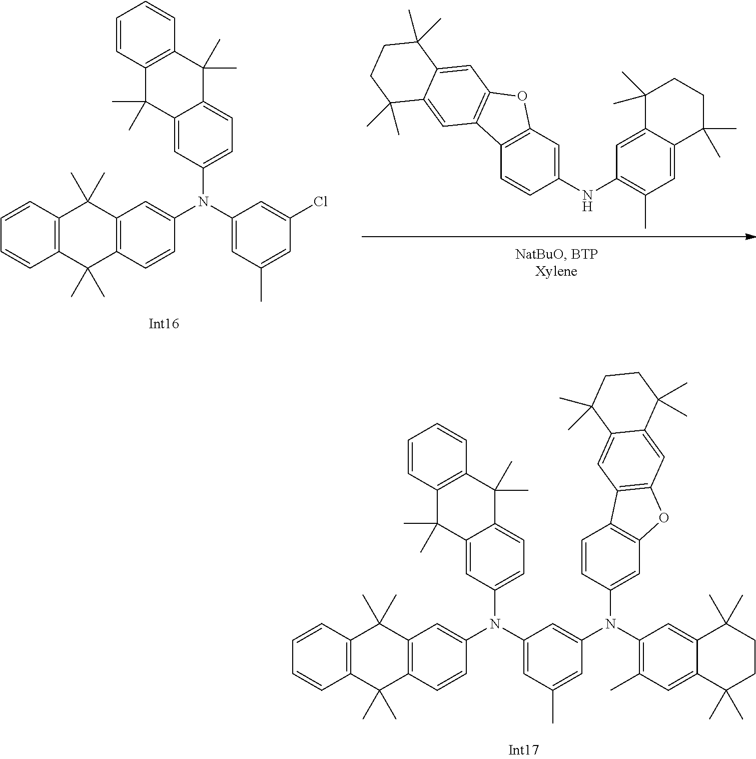

After introducing Int16 (30 g), 7,7,10,10-tetramethyl-N-(3,5,5,8,8-pentamethyl-5,6,7,8-tetrahydronaphthalen-2-yl)-7,8,9,10-tetrahydronaphtha[2,3-b]benzofuran-3-amine (24.3 g), sodium-tert-butoxide (15 g) and bis(tri-tert-butylphosphine)palladium(0) (0.5 g) to xylene (600 ml), the mixture was refluxed for 6 hours. After the reaction was finished, the result was extracted and then recrystallized to obtain Int17 (37 g, yield 71%). MS[M+H]+=1068

### 3) Synthesis of Compound M15

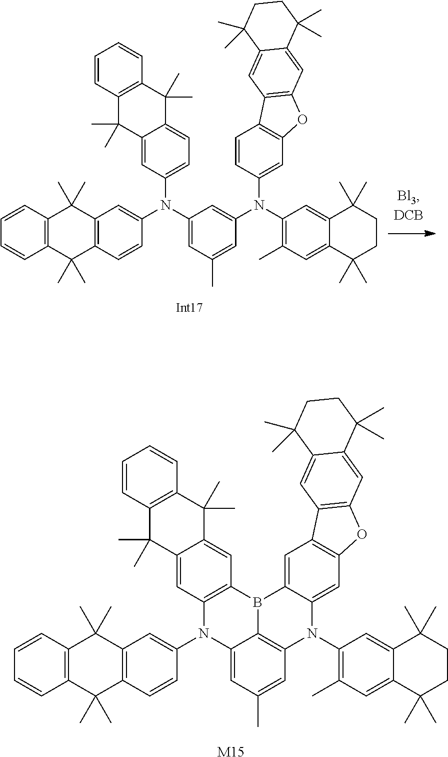

After introducing Int17 (25 g) and boron triiodide (15.6 g) to 1,2-dichlorobenzene (250 ml) under a nitrogen atmosphere, the mixture was stirred for 8 hours at 160° C. After the reaction was finished, the result was extracted and then recrystallized to obtain Compound M15 (7.7 g, yield 31%). MS[M+H]+=1076

### Synthesis Example 16. Synthesis of Compound M16

### 1) Synthesis of Int18

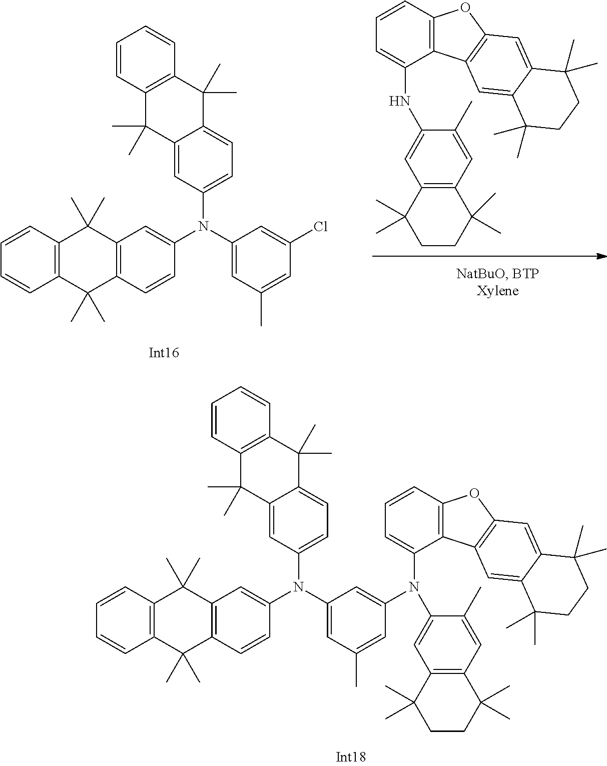 [SMILES: Cc1cc(Cl)cc(N(c2ccc3c(c2)C(C)(C)c2ccccc2C3(C)C)c2ccc3c(c2)C(C)(C)c2ccccc2C3(C)C)c1 ; Cc1cc2c(cc1Nc1cccc3oc4cc5c(cc4c13)C(C)(C)CCC5(C)C)C(C)(C)CCC2(C)C ; Cc1cc(N(c2ccc3c(c2)C(C)(C)c2ccccc2C3(C)C)c2ccc3c(c2)C(C)(C)c2ccccc2C3(C)C)cc(N(c2cc3c(cc2C)C(C)(C)CCC3(C)C)c2cccc3oc4cc5c(cc4c23)C(C)(C)CCC5(C)C)c1]

After introducing Int16 (30 g), 7,7,10,10-tetramethyl-N-(3,5,5,8,8-pentamethyl-5,6,7,8-tetrahydronaphthalen-2-yl)-7,8,9,10-tetrahydronaphtha[2,3-b]benzofuran-1-amine (24.3 g), sodium-tert-butoxide (15 g) and bis(tri-tert-butylphosphine)palladium(0) (0.5 g) to xylene (600 ml), the mixture was refluxed for 6 hours. After the reaction was finished, the result was extracted and then recrystallized to obtain Int18 (39 g, yield 74%). MS[M+H]+=1068

### 2) Synthesis of Compound M16

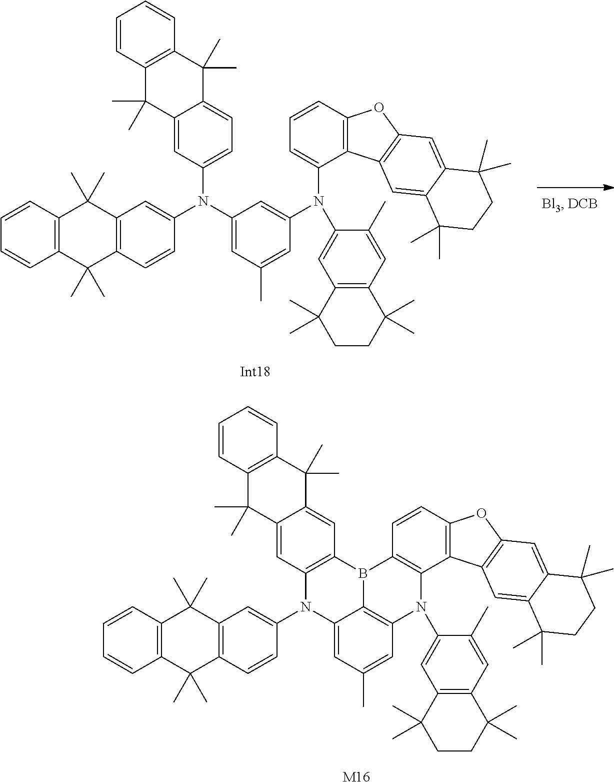 [SMILES: Cc1cc(N(c2ccc3c(c2)C(C)(C)c2ccccc2C3(C)C)c2ccc3c(c2)C(C)(C)c2ccccc2C3(C)C)cc(N(c2cc3c(cc2C)C(C)(C)CCC3(C)C)c2cccc3oc4cc5c(cc4c23)C(C)(C)CCC5(C)C)c1 ; Cc1cc2c3c(c1)N(c1cc4c(cc1C)C(C)(C)CCC4(C)C)c1c(ccc4oc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; "M16"]

After introducing Int18 (25 g) and boron triiodide (15.6 g) to 1,2-dichlorobenzene (250 ml) under a nitrogen atmosphere, the mixture was stirred for 8 hours at 160° C. After the reaction was finished, the result was extracted and then recrystallized to obtain Compound M16 (7.9 g, yield 31%). MS[M+H]+=1076

### Synthesis Example 17. Synthesis of Compound M17

### 1) Synthesis of Int19

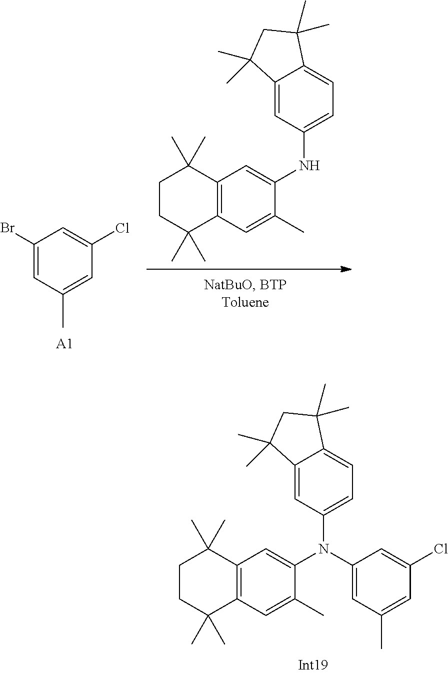

After introducing 1-bromo-3-chloro-5-methylbenzene (30 g), 3,5,5,8,8-pentamethyl-N-(1,1,3,3-tetramethyl-2,3-dihydro-1H-inden-5-yl)-5,6,7,8-tetrahydro-naphthalen-2-amine (56.9 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int19 (54 g, yield 72%). MS[M+H]+=515

### 2) Synthesis of Int20

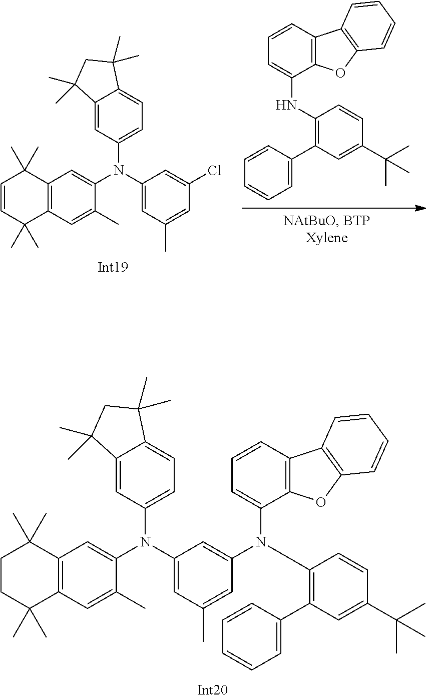

After introducing Int19 (30 g), N-(5-(tert-butyl)-[1,1′-biphenyl]-2-yl)dibenzo[b,d]furan-4-amine (22.8 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int20 (36 g, yield 71%). MS[M+H]+=870

### 3) Synthesis of Compound M17

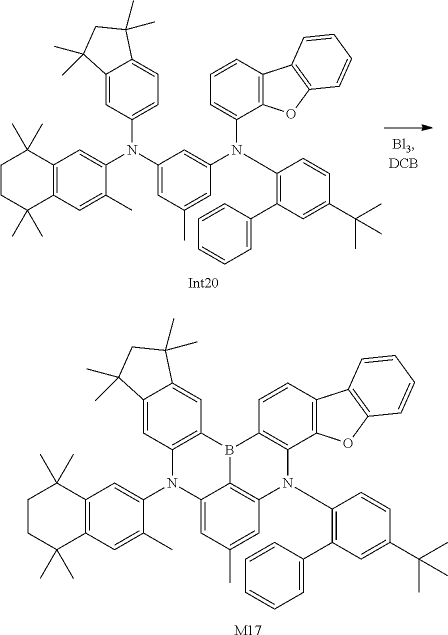

After introducing Int20 (25 g) and boron triiodide (15.6 g) to 1,2-dichlorobenzene (250 ml) under a nitrogen atmosphere, the mixture was stirred for 8 hours at 160° C. After the reaction was finished, the result was extracted and then recrystallized to obtain Compound M17 (7.3 g, yield 29%). MS[M+H]+=878

### Synthesis Example 18. Synthesis of Compound M18

### 1) Synthesis of Int21

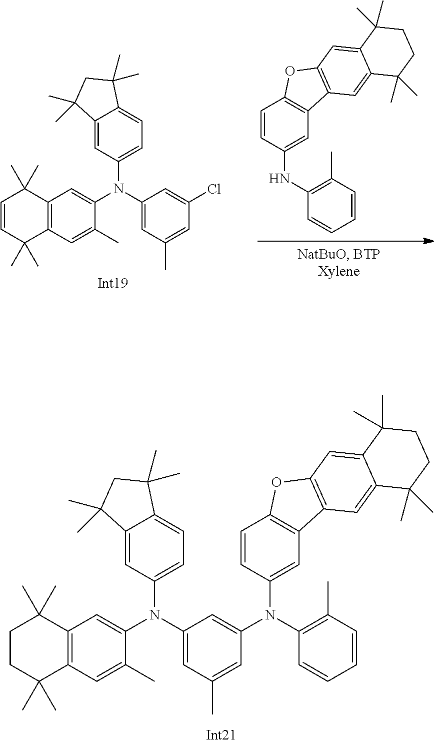 [SMILES: Cc1cc(Cl)cc(N(c2ccc3c(c2)C(C)(C)CC3(C)C)c2cc3c(cc2C)C(C)(C)C=CC3(C)C)c1 ; Cc1ccccc1Nc1ccc2oc3cc4c(cc3c2c1)C(C)(C)CCC4(C)C ; Cc1cc(N(c2ccc3oc4cc5c(cc4c3c2)C(C)(C)CCC5(C)C)c2ccccc2C)cc(N(c2ccc3c(c2)C(C)(C)CC3(C)C)c2cc3c(cc2C)C(C)(C)CCC3(C)C)c1]

After introducing Int19 (30 g), 7,7,10,10-tetramethyl-N-(o-tolyl)-7,8,9,10-tetrahydronaphtho[2,3-b]benzofuran-2-amine (22.4 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int21 (36 g, yield 72%). MS[M+H]+=862

### 2) Synthesis of Compound M18

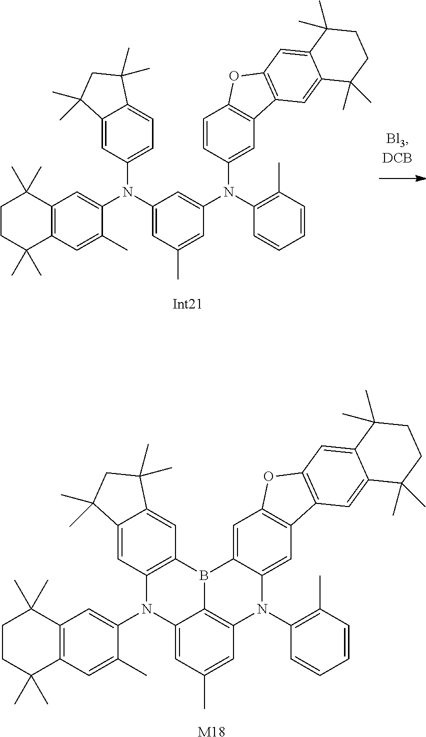

After introducing Int21 (25 g) and boron triiodide (19.3 g) to 1,2-dichlorobenzene (250 ml) under a nitrogen atmosphere, the mixture was stirred for 8 hours at 160° C. After the reaction was finished, the result was extracted and then recrystallized to obtain Compound M18 (7.5 g, yield 30%). MS[M+H]+=870

### Synthesis Example 19. Synthesis of Compound M19

### 1) Synthesis of Int22

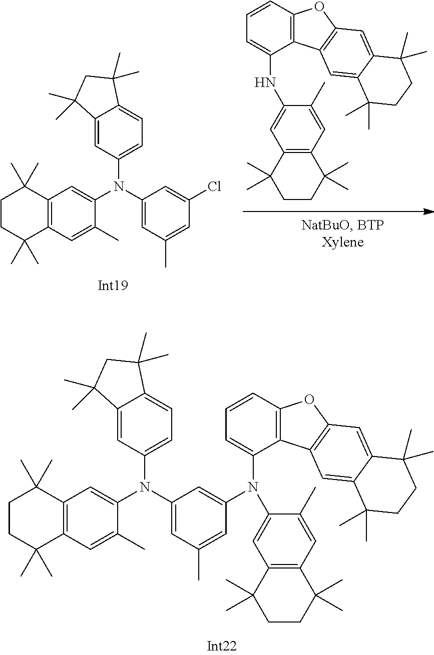

After introducing Int19 (30 g), 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-1-amine (28.8 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int22 (44 g, yield 78%). MS[M+H]+=972

### 2) Synthesis of Compound M19

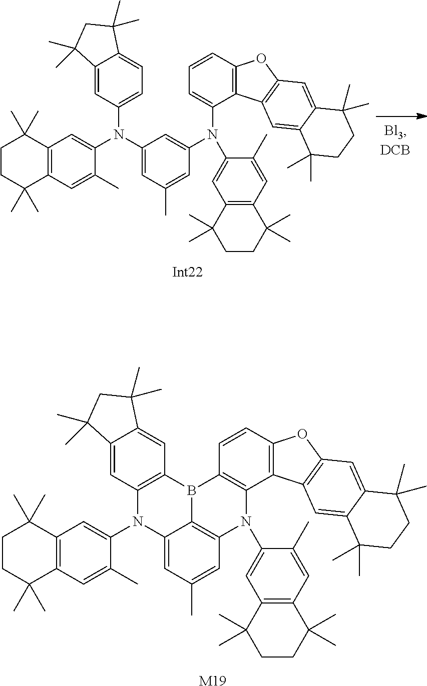

After introducing Int22 (25 g) and boron triiodide (17.2 g) to 1,2-dichlorobenzene (250 ml) under a nitrogen atmosphere, the mixture was stirred for 8 hours at 160° C. After the reaction was finished, the result was extracted and then recrystallized to obtain Compound M19 (7.4 g, yield 29%). MS[M+H]+=980

### Synthesis Example 20. Synthesis of Compound M20

### 1) Synthesis of Int23

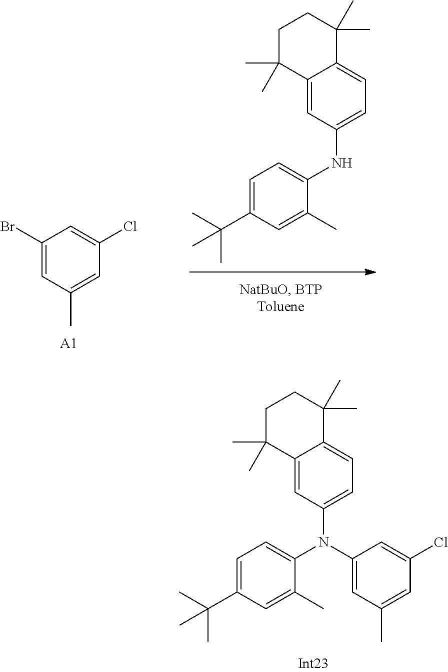

After introducing 1-bromo-3-chloro-5-methylbenzene (30 g), N-(4-(tert-butyl)-2-methylphenyl)-5,5,8,8-tetramethyl-5,6,7,8-tetrahydronaphthalen-2-amine (51.1 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int23 (53 g, yield 77%). MS[M+H]+=475

### 2) Synthesis of Int24

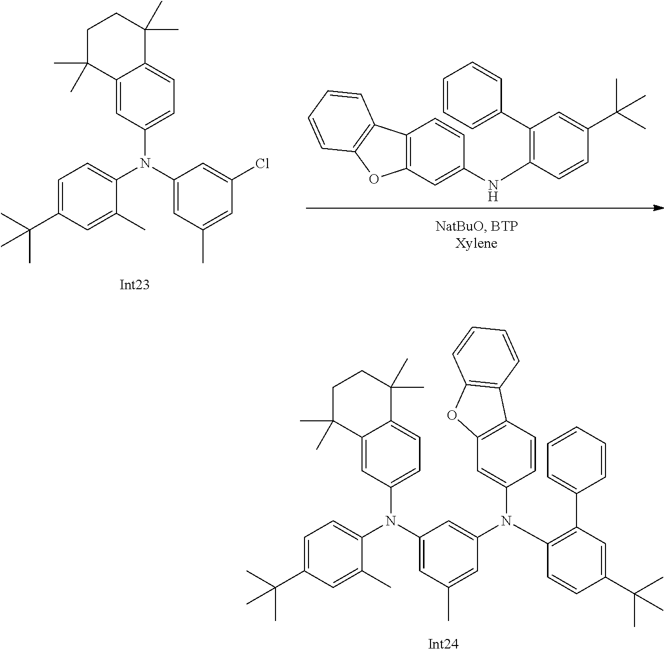 [SMILES: Cc1cc(Cl)cc(N(c2ccc3c(c2)C(C)(C)CCC3(C)C)c2ccc(C(C)(C)C)cc2C)c1 ; CC(C)(C)c1ccc(Nc2ccc3c(c2)oc2ccccc23)c(-c2ccccc2)c1 ; Cc1cc(N(c2ccc3c(c2)C(C)(C)CCC3(C)C)c2ccc(C(C)(C)C)cc2C)cc(N(c2ccc3c(c2)oc2ccccc23)c2ccc(C(C)(C)C)cc2-c2ccccc2)c1]

After introducing Int23 (30 g), N-(5-(tert-butyl)-[1,1′-biphenyl]-2-yl)dibenzo[b,d]furan-3-amine (24.8 g), sodium-tert-butoxide (18.3 g) and bis(tri-tert-butylphosphine)palladium(0) (0.65 g) to xylene (600 ml), the mixture was refluxed for 6 hours. After the reaction was finished, the result was extracted and then recrystallized to obtain Int24 (39 g, yield 74%). MS[M+H]+=830

### 3) Synthesis of Compound M20

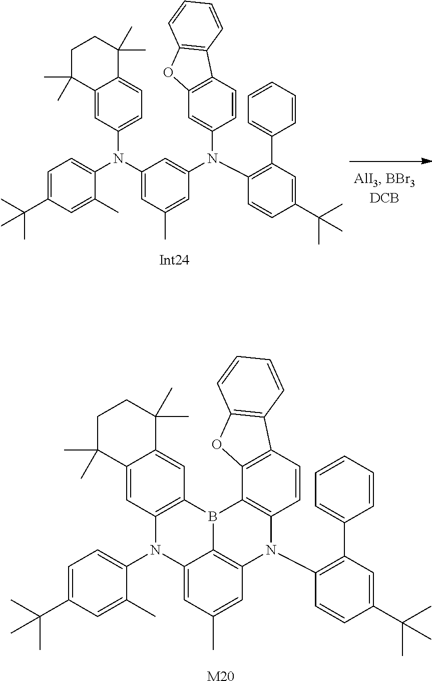

After introducing Int24 (25 g), aluminum iodide (4.9 g) and boron tribromide (22.8 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M20 (7.5 g, yield 30%). MS[M+H]+=838

### Synthesis Example 21. Synthesis of Compound M21

### 1) Synthesis of Int25

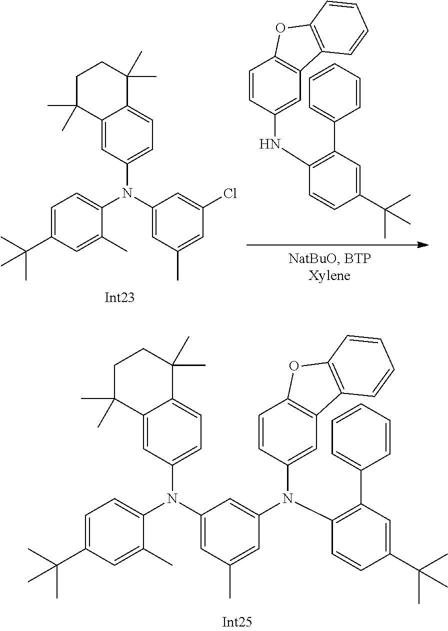 [SMILES: Cc1cc(Cl)cc(N(c2ccc3c(c2)C(C)(C)CCC3(C)C)c2ccc(C(C)(C)C)cc2C)c1 ; CC(C)(C)c1ccc(Nc2ccc3oc4ccccc4c3c2)c(-c2ccccc2)c1 ; Cc1cc(N(c2ccc3c(c2)C(C)(C)CCC3(C)C)c2ccc(C(C)(C)C)cc2C)cc(N(c2ccc3oc4ccccc4c3c2)c2ccc(C(C)(C)C)cc2-c2ccccc2)c1]

After introducing Int23 (30 g), N-(5-(tert-butyl)-[1,1′-biphenyl]-2-yl)dibenzo[b,d]furan-2-amine (24.8 g), sodium-tert-butoxide (18.3 g) and bis(tri-tert-butylphosphine)palladium(0) (0.65 g) to xylene (600 ml), the mixture was refluxed for 6 hours. After the reaction was finished, the result was extracted and then recrystallized to obtain Int25 (39 g, yield 74%). MS[M+H]+=830

### 2) Synthesis of Compound M21

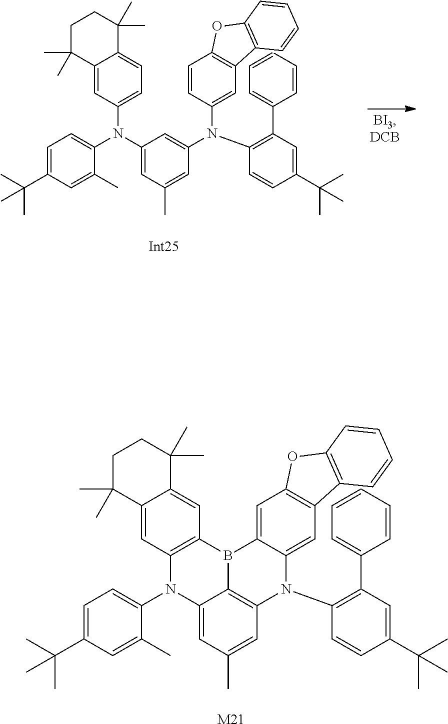

After introducing Int25 (25 g) and boron triiodide (20 g) to 1,2-dichlorobenzene (250 ml) under a nitrogen atmosphere, the mixture was stirred for 8 hours at 160° C. After the reaction was finished, the result was extracted and then recrystallized to obtain Compound M21 (7.7 g, yield 31%). MS[M+H]+=838

### Synthesis Example 22. Synthesis of Compound M22

### 1) Synthesis of Int26

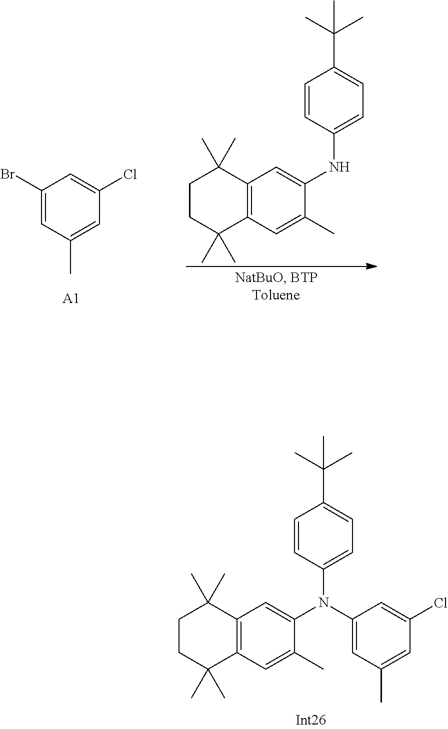

After introducing 1-bromo-3-chloro-5-methylbenzene (30 g), N-(4-(tert-butyl)phenyl)-3,5,5,8,8-pentamethyl-5,6,7,8-tetrahydronaphthalen-2-amine (51.1 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int26 (52 g, yield 75%). MS[M+H]+=475

### 2) Synthesis of Int27

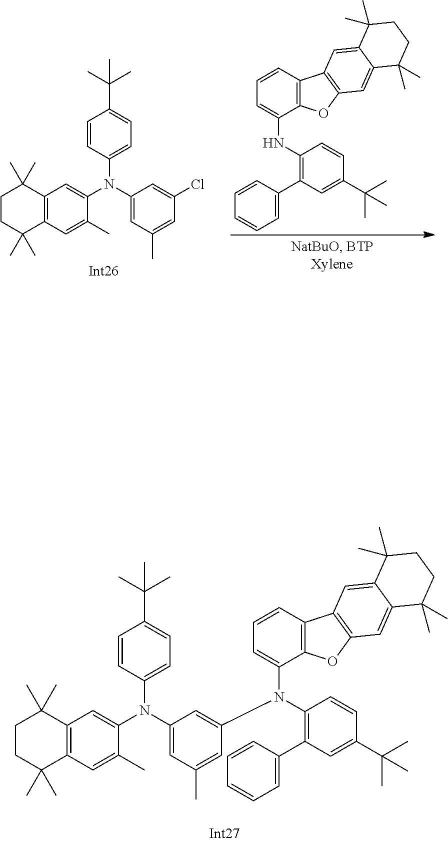 [SMILES: Cc1cc(Cl)cc(N(c2ccc(C(C)(C)C)cc2)c2cc3c(cc2C)C(C)(C)CCC3(C)C)c1 ; CC(C)(C)c1ccc(Nc2cccc3c2oc2cc4c(cc23)C(C)(C)CCC4(C)C)c(-c2ccccc2)c1 ; Cc1cc(N(c2ccc(C(C)(C)C)cc2)c2cc3c(cc2C)C(C)(C)CCC3(C)C)cc(N(c2ccc(C(C)(C)C)cc2-c2ccccc2)c2cccc3c2oc2cc4c(cc23)C(C)(C)CCC4(C)C)c1]

After introducing Int26 (30 g), N-(5-(tert-butyl)-[1,1′-biphenyl]-2-yl)-7,7,10,10-tetramethyl-7,8,9,10-tetrahydronaphtho[2,3-b]benzofuran-4-amine (31.7 g), sodium-tert-butoxide (18.2 g) and bis(tri-tert-butylphosphine)palladium(0) (0.65 g) to xylene (600 ml), the mixture was refluxed for 6 hours. After the reaction was finished, the result was extracted and then recrystallized to obtain Int27 (45 g, yield 76%). MS[M+H]+=940

### 3) Synthesis of Compound M22

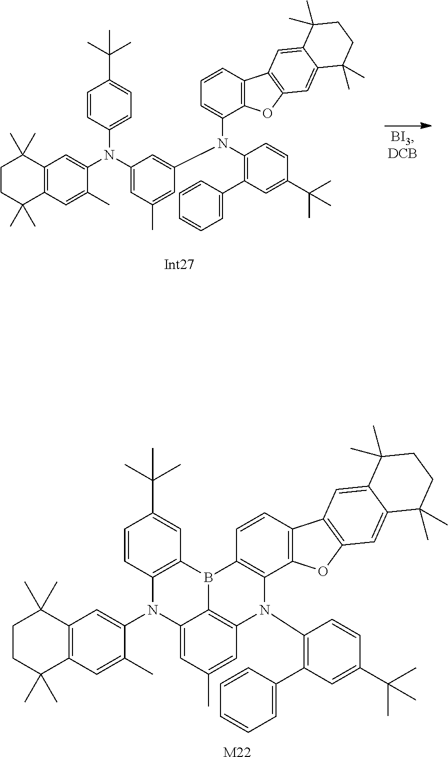

After introducing Int27 (25 g) and boron triiodide (17.7 g) to 1,2-dichlorobenzene (250 ml) under a nitrogen atmosphere, the mixture was stirred for 8 hours at 160° C. After the reaction was finished, the result was extracted and then recrystallized to obtain Compound M22 (7.4 g, yield 29%). MS[M+H]+=948

### Synthesis Example 23. Synthesis of Compound M23

### 1) Synthesis of Int28

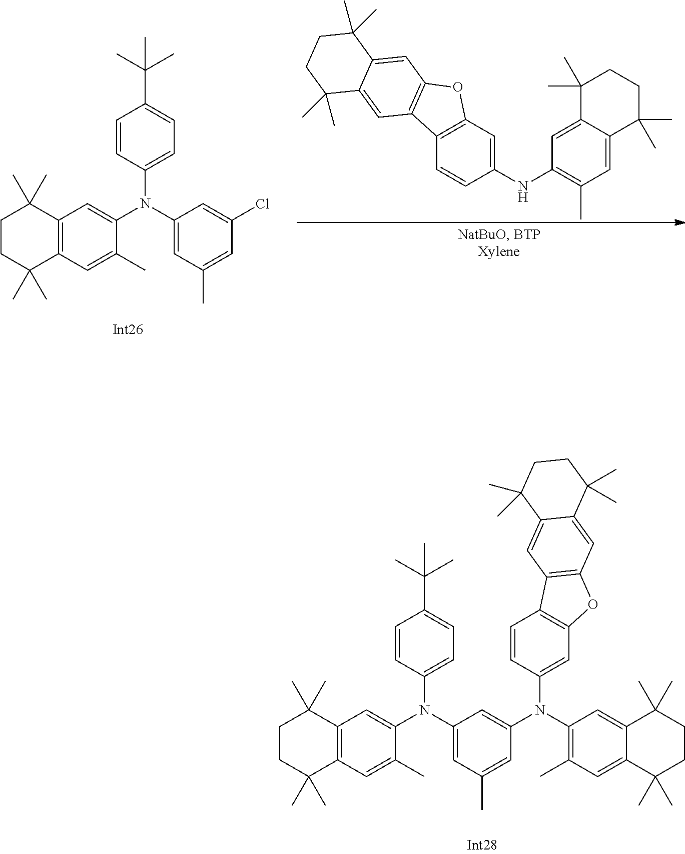

After introducing Int26 (30 g), 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-3-amine (31.2 g), sodium-tert-butoxide (18.2 g) and bis(tri-tert-butylphosphine)palladium(0) (0.65 g) to xylene (600 ml), the mixture was refluxed for 6 hours. After the reaction was finished, the result was extracted and then recrystallized to obtain Int28 (44 g, yield 75%). MS[M+H]+=932

### 2) Synthesis of Compound M23

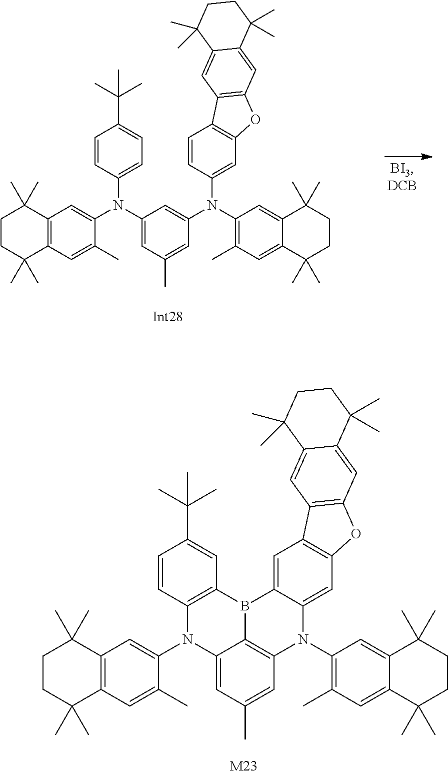

After introducing Int28 (25 g) and boron triiodide (17.9 g) to 1,2-dichlorobenzene (250 ml) under a nitrogen atmosphere, the mixture was stirred for 8 hours at 160° C. After the reaction was finished, the result was extracted and then recrystallized to obtain Compound M23 (7.5 g, yield 30%). MS[M+H]+=940

### Synthesis Example 24. Synthesis of Compound M24

### 1) Synthesis of Int29

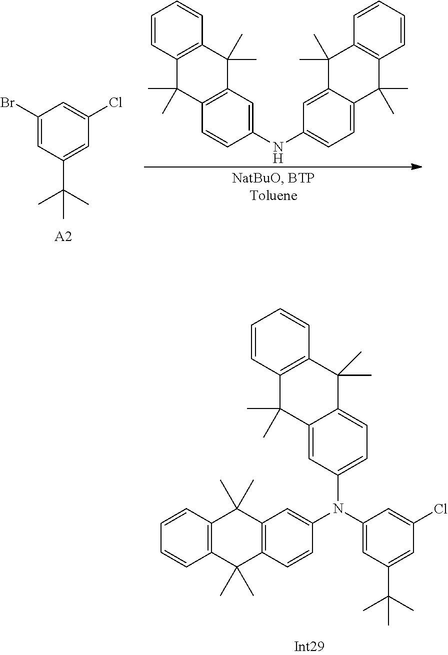

After introducing 1-bromo-3-(tert-butyl)-5-chlorobenzene (30 g), bis(9,9,10,10-tetramethyl-9,10-dihydroanthracen-2-yl)amine (58.9 g), sodium-tert-butoxide (35 g) and bis(tri-tert-butylphosphine)palladium(0) (1.3 g) to toluene (600 ml), the mixture was refluxed for 1 hour. After the reaction was finished, the result was extracted, and then recrystallized to obtain Int29 (56 g, yield 71%). MS[M+H]+=653

### 2) Synthesis of Int30

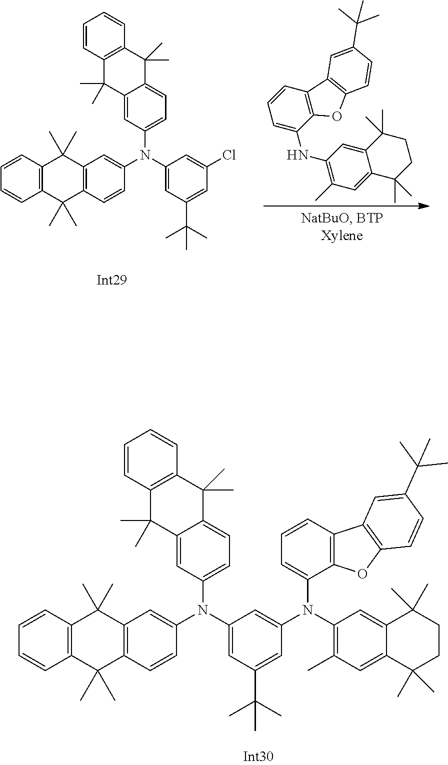 [SMILES: CC(C)(C)c1cc(Cl)cc(N(c2ccc3c(c2)C(C)(C)c2ccccc2C3(C)C)c2ccc3c(c2)C(C)(C)c2ccccc2C3(C)C)c1 ; Cc1cc2c(cc1Nc1cccc3c1oc1ccc(C(C)(C)C)cc13)C(C)(C)CCC2(C)C ; Cc1cc2c(cc1N(c1cc(N(c3ccc4c(c3)C(C)(C)c3ccccc3C4(C)C)c3ccc4c(c3)C(C)(C)c3ccccc3C4(C)C)cc(C(C)(C)C)c1)c1cccc3c1oc1ccc(C(C)(C)C)cc13)C(C)(C)CCC2(C)C]

After introducing Int29 (30 g), 8-(tert-butyl)-N-(3,5,5,8,8-pentamethyl-5,6,7,8-tetrahydronaphthalen-2-yl)dibenzo[b,d]furan-4-amine (20.2 g), sodium-tert-butoxide (13.3 g) and bis(tri-tert-butylphosphine)palladium(0) (0.5 g) to xylene (600 ml), the mixture was refluxed for 6 hours. After the reaction was finished, the result was extracted and then recrystallized to obtain Int30 (34 g, yield 70%). MS[M+H]+=1056

### 3) Synthesis of Compound M24

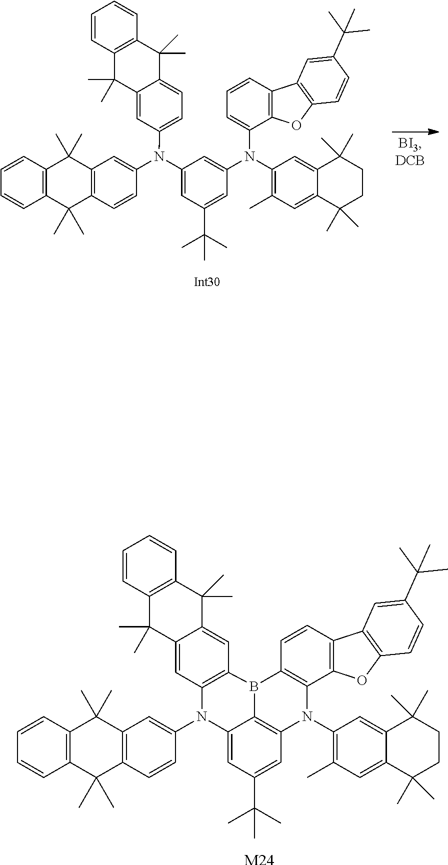

After introducing Int30 (25 g) and boron triiodide (15.8 g) to 1,2-dichlorobenzene (250 ml) under a nitrogen atmosphere, the mixture was stirred for 8 hours at 160° C. After the reaction was finished, the result was extracted and then recrystallized to obtain Compound M24 (7.5 g, yield 30%). MS[M+H]+=1064

### Synthesis Example 25. Synthesis of Compound M25

### 1) Synthesis of Int31

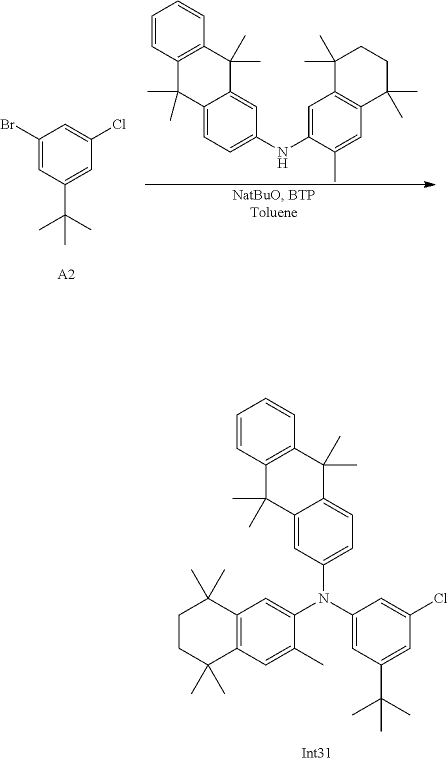

After introducing A2 (30 g), 9,9,10,10-tetramethyl-N-(3,5,5,8,8-pentamethyl-5,6,7,8-tetrahydronaphthalen-2-yl)-9,10-dihydroanthracen-2-amine (54.8 g), sodium-tert-butoxide (35 g) and bis(tri-tert-butylphosphine)palladium(0) (1.3 g) to toluene (600 ml), the mixture was refluxed for 1 hour. After the reaction was finished, the result was extracted, and then recrystallized to obtain Int31 (55 g, yield 73%). MS[M+H]+=619

### 2) Synthesis of Int32

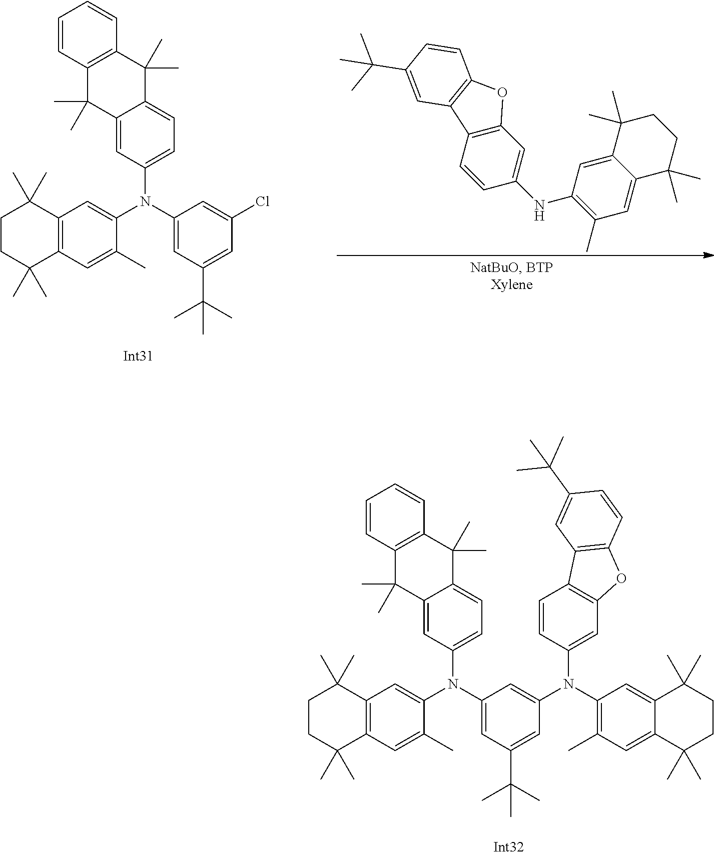 [SMILES: Cc1cc2c(cc1N(c1cc(Cl)cc(C(C)(C)C)c1)c1ccc3c(c1)C(C)(C)c1ccccc1C3(C)C)C(C)(C)CCC2(C)C ; Cc1cc2c(cc1Nc1ccc3c(c1)oc1ccc(C(C)(C)C)cc13)C(C)(C)CCC2(C)C ; Cc1cc2c(cc1N(c1cc(N(c3ccc4c(c3)oc3ccc(C(C)(C)C)cc34)c3cc4c(cc3C)C(C)(C)CCC4(C)C)cc(C(C)(C)C)c1)c1ccc3c(c1)C(C)(C)c1ccccc1C3(C)C)C(C)(C)CCC2(C)C]

After introducing Int31 (30 g), 8-(tert-butyl)-N-(3,5,5,8,8-pentamethyl-5,6,7,8-tetrahydronaphthalen-2-yl)dibenzo[b,d]furan-3-amine (21.3 g), sodium-tert-butoxide (13.9 g) and bis(tri-tert-butylphosphine)palladium(0) (0.5 g) to xylene (600 ml), the mixture was refluxed for 6 hours. After the reaction was finished, the result was extracted and then recrystallized to obtain Int32 (36 g, yield 73%). MS[M+H]+=1022

### 3) Synthesis of Compound M25

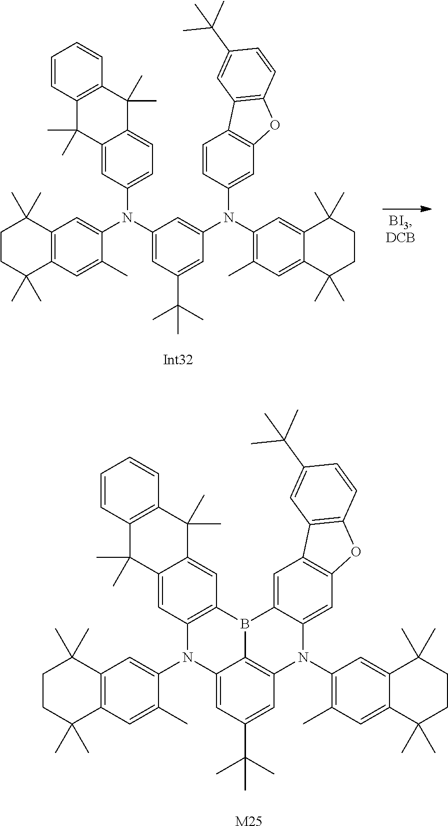

After introducing Int32 (25 g) and boron triiodide (16.3 g) to 1,2-dichlorobenzene (250 ml) under a nitrogen atmosphere, the mixture was stirred for 8 hours at 160° C. After the reaction was finished, the result was extracted and then recrystallized to obtain Compound M25 (7.6 g, yield 30%). MS[M+H]+=1030

### Synthesis Example 26. Synthesis of Compound M26

### 1) Synthesis of Int33

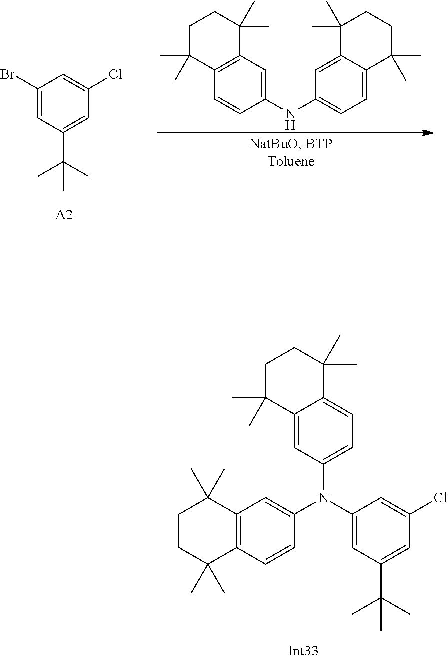

After introducing A2 (30 g), bis(5,5,8,8-tetramethyl-5,6,7,8-tetrahydronaphthalen-2-yl)amine (47.2 g), sodium-tert-butoxide (35 g) and bis(tri-tert-butylphosphine)-palladium(0) (1.3 g) to toluene (600 ml), the mixture was refluxed for 1 hour. After the reaction was finished, the result was extracted, and then recrystallized to obtain Int33 (52 g, yield 77%). MS[M+H]+=557

### 2) Synthesis of Int34

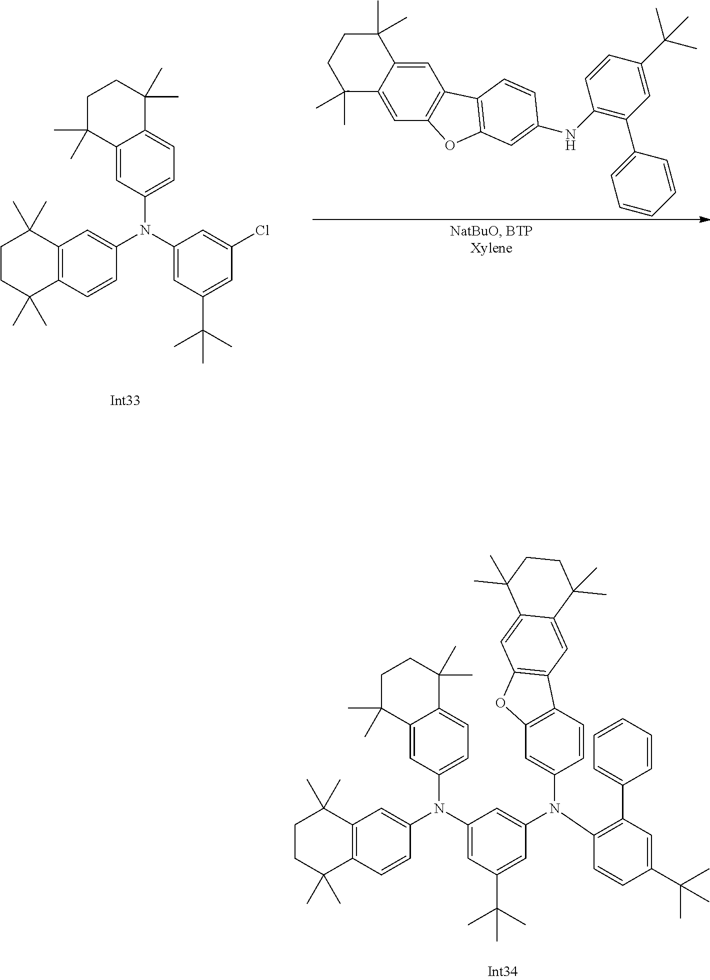

After introducing Int33 (33 g), N-(5-(tert-butyl)-[1,1′-biphenyl]-2-yl)-7,7,10,10-tetramethyl-7,8,9,10-tetrahydronaphtho[2,3-b]benzofuran-3-amine (27.1 g), sodium-tert-butoxide (15.5 g) and bis(tri-tert-butylphosphine)palladium(0) (0.6 g) to xylene (600 ml), the mixture was refluxed for 6 hours. After the reaction was finished, the result was extracted and then recrystallized to obtain Int34 (39 g, yield 71%). MS[M+H]+=1022

### 3) Synthesis of Compound M26

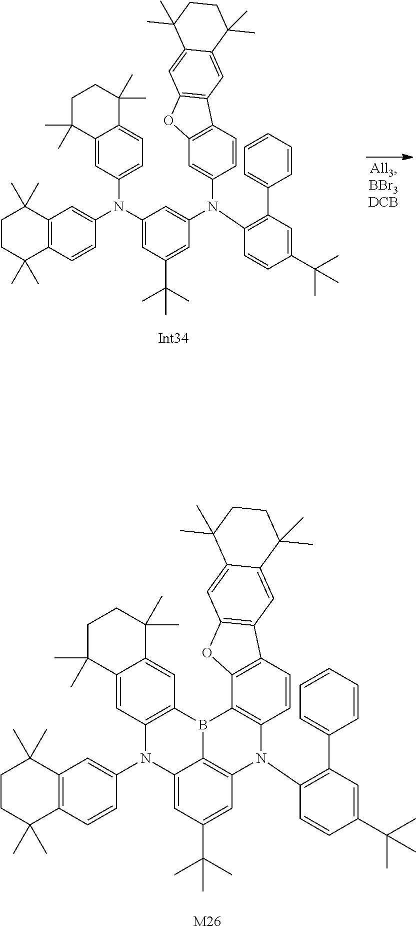

After introducing Int34 (25 g), aluminum iodide (4 g) and boron tribromide (18.5 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M26 (7.6 g, yield 30%). MS[M+H]+=1030

### Synthesis Example 27. Synthesis of Compound M27

### 1) Synthesis of Int35

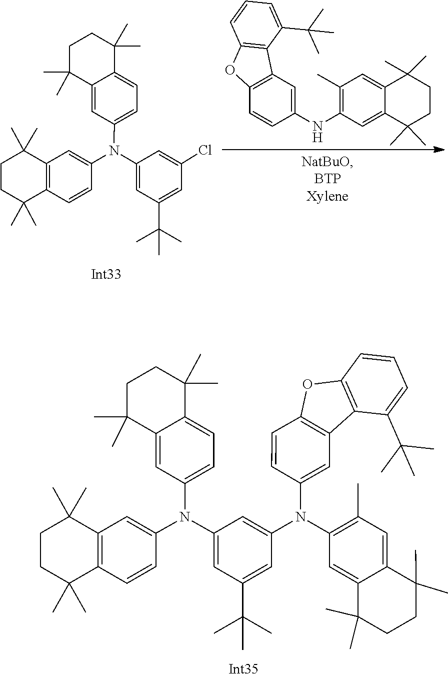 [SMILES: CC(C)(C)c1cc(Cl)cc(N(c2ccc3c(c2)C(C)(C)CCC3(C)C)c2ccc3c(c2)C(C)(C)CCC3(C)C)c1 ; Cc1cc2c(cc1Nc1ccc3oc4cccc(C(C)(C)C)c4c3c1)C(C)(C)CCC2(C)C ; Cc1cc2c(cc1N(c1cc(N(c3ccc4c(c3)C(C)(C)CCC4(C)C)c3ccc4c(c3)C(C)(C)CCC4(C)C)cc(C(C)(C)C)c1)c1ccc3oc4cccc(C(C)(C)C)c4c3c1)C(C)(C)CCC2(C)C]

After introducing Int33 (33 g), 9-(tert-butyl)-N-(3,5,5,8,8-pentamethyl-5,6,7,8-tetrahydronaphthalen-2-yl)dibenzo[b,d]furan-2-amine (23.7 g), sodium-tert-butoxide (15.5 g) and bis(tri-tert-butylphosphine)palladium(0) (0.6 g) to xylene (600 ml), the mixture was refluxed for 6 hours. After the reaction was finished, the result was extracted and then recrystallized to obtain Int35 (36 g, yield 70%). MS[M+H]+=960

### 2) Synthesis of Compound M27

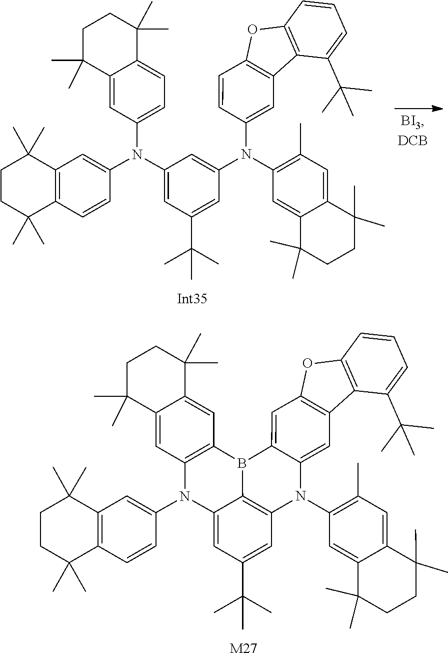

After introducing Int35 (25 g) and boron triiodide (17.3 g) to 1,2-dichlorobenzene (250 ml) under a nitrogen atmosphere, the mixture was stirred for 8 hours at 160° C. After the reaction was finished, the result was extracted and then recrystallized to obtain Compound M27 (7.9 g, yield 31%). MS[M+H]+=968

### Synthesis Example 28. Synthesis of Compound M28

### 1) Synthesis of Int36

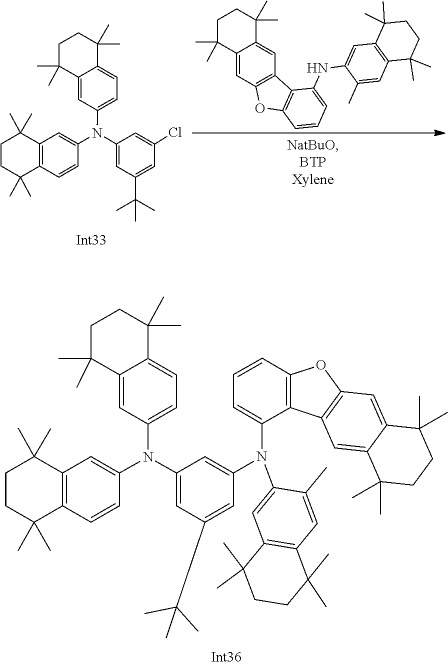

After introducing Int33 (33 g), 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-1-amine (26.3 g), sodium-tert-butoxide (15.5 g) and bis(tri-tert-butylphosphine)palladium(0) (0.6 g) to xylene (600 ml), the mixture was refluxed for 6 hours. After the reaction was finished, the result was extracted and then recrystallized to obtain Int36 (39 g, yield 71%). MS[M+H]+=1014

### 2) Synthesis of Compound M28

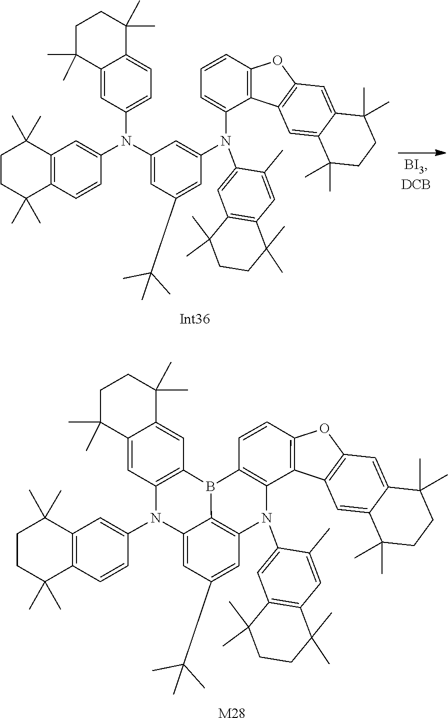

After introducing Int36 (25 g) and boron triiodide (16.4 g) to 1,2-dichlorobenzene (250 ml) under a nitrogen atmosphere, the mixture was stirred for 8 hours at 160° C. After the reaction was finished, the result was extracted and then recrystallized to obtain Compound M28 (7.4 g, yield 29%). MS[M+H]+=1022

### Synthesis Example 29. Synthesis of Compound M29

### 1) Synthesis of Int37

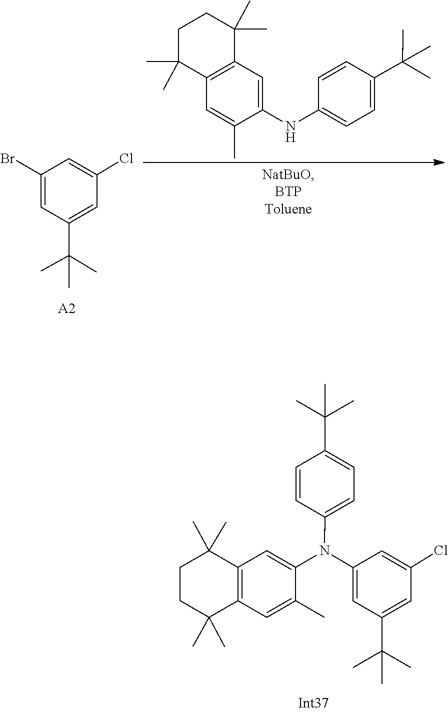

After introducing A2 (30 g), N-(4-(tert-butyl)phenyl)-3,5,5,8,8-pentamethyl-5,6,7,8-tetrahydronaphthalen-2-amine (42.4 g), sodium-tert-butoxide (35 g) and bis(tri-tert-butylphosphine)palladium(0) (1.3 g) to toluene (600 ml), the mixture was refluxed for 1 hour. After the reaction was finished, the result was extracted, and then recrystallized to obtain Int37 (48 g, yield 77%). MS[M+H]+=517

### 2) Synthesis of Int38

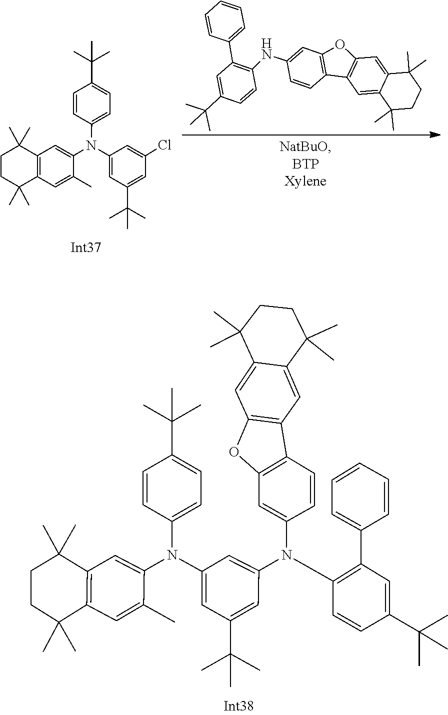

After introducing Int37 (30 g), N-(5-(tert-butyl)-[1,1′-biphenyl]-2-yl)-7,7,10,10-tetramethyl-7,8,9,10-tetrahydronaphtho[2,3-b]benzofuran-3-amine (29.2 g), sodium-tert-butoxide (16.8 g) and bis(tri-tert-butylphosphine)palladium(0) (0.6 g) to xylene (600 ml), the mixture was refluxed for 6 hours. After the reaction was finished, the result was extracted and then recrystallized to obtain Int38 (41 g, yield 72%). MS[M+H]+=982

### 3) Synthesis of Compound M29

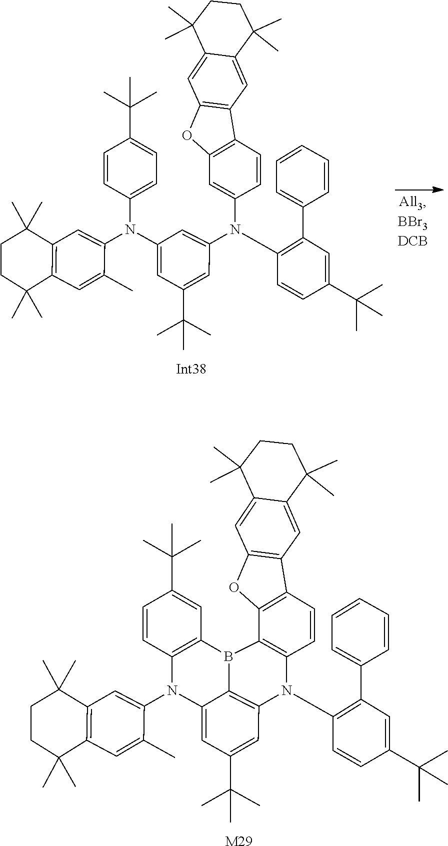

After introducing Int38 (25 g), aluminum iodide (4.2 g) and boron tribromide (19.3 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M29 (7.7 g, yield 31%). MS[M+H]+=990

### Synthesis Example 30. Synthesis of Compound M30

### 1) Synthesis of Int39

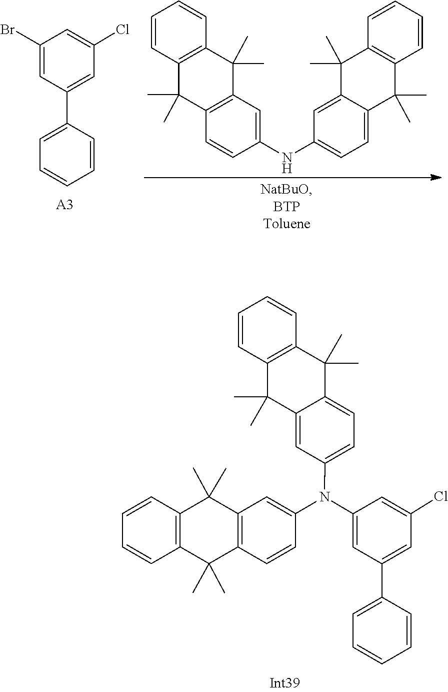

After introducing 3-bromo-5-chloro-1,1′-biphenyl (30 g), bis(9,9,10,10-tetramethyl-9,10-dihydroanthracen-2-yl)amine (54.5 g), sodium-tert-butoxide (32.4 g) and bis(tri-tert-butylphosphine)palladium(0) (1.2 g) to toluene (600 ml), the mixture was refluxed for 1 hour. After the reaction was finished, the result was extracted, and then recrystallized to obtain Int39 (54 g, yield 72%). MS[M+H]+=673

### 2) Synthesis of Int40

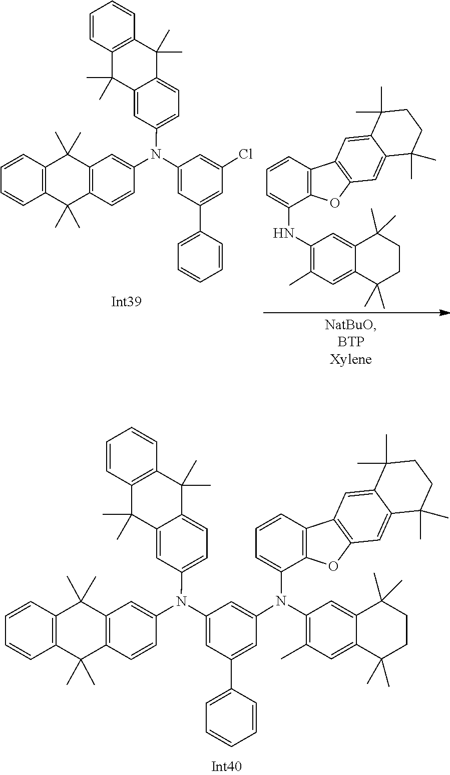

After introducing Int39 (30 g), 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-4-amine (22.1 g), sodium-tert-butoxide (12.9 g) and bis(tri-tert-butylphosphine)palladium(0) (0.5 g) to xylene (600 ml), the mixture was refluxed for 6 hours. After the reaction was finished, the result was extracted and then recrystallized to obtain Int40 (37 g, yield 73%). MS[M+H]+=1130

### 3) Synthesis of Compound M30

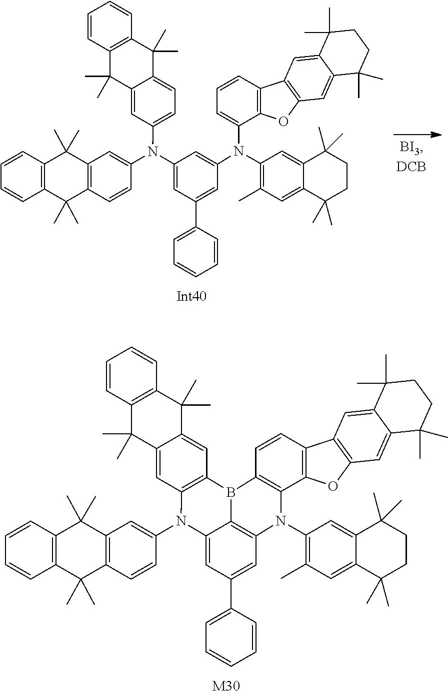

After introducing Int40 (25 g) and boron triiodide (14.8 g) to 1,2-dichlorobenzene (250 ml) under a nitrogen atmosphere, the mixture was stirred for 8 hours at 160° C. After the reaction was finished, the result was extracted and then recrystallized to obtain Compound M30 (7.5 g, yield 30%). MS[M+H]+=1138

### Synthesis Example 31. Synthesis of Compound M31

### 1) Synthesis of Int41

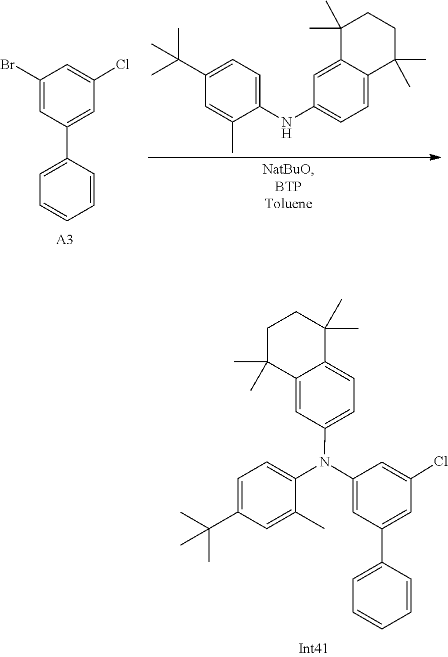

After introducing A3 (30 g), N-(4-(tert-butyl)-2-methylphenyl)-5,5,8,8-tetramethyl-5,6,7,8-tetrahydro-naphthalen-2-amine (39.2 g), sodium-tert-butoxide (32.3 g) and bis(tri-tert-butylphosphine)palladium(0) (1.2 g) to toluene (600 ml), the mixture was refluxed for 1 hour. After the reaction was finished, the result was extracted, and then recrystallized to obtain Int41 (44 g, yield 73%). MS[M+H]+=537

### 2) Synthesis of Int42

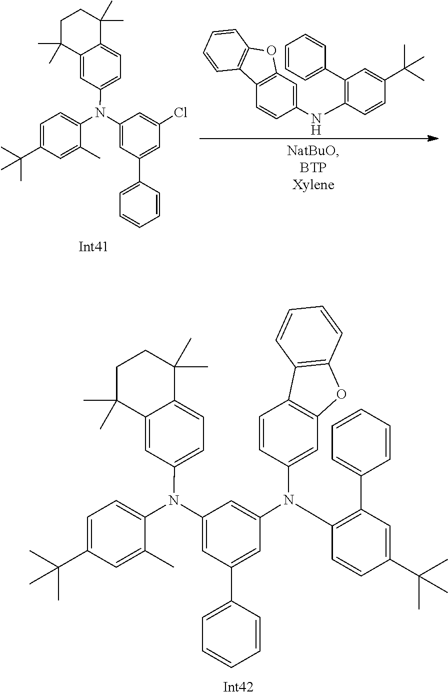 [SMILES: Cc1cc(C(C)(C)C)ccc1N(c1cc(Cl)cc(-c2ccccc2)c1)c1ccc2c(c1)C(C)(C)CCC2(C)C ; CC(C)(C)c1ccc(Nc2ccc3c(c2)oc2ccccc23)c(-c2ccccc2)c1 ; Cc1cc(C(C)(C)C)ccc1N(c1cc(-c2ccccc2)cc(N(c2ccc3c(c2)oc2ccccc23)c2ccc(C(C)(C)C)cc2-c2ccccc2)c1)c1ccc2c(c1)C(C)(C)CCC2(C)C]

After introducing Int41 (30 g), N-(5-(tert-butyl)-[1,1′-biphenyl]-2-yl)dibenzo[b,d]furan-3-amine (21.9 g), sodium-tert-butoxide (16.1 g) and bis(tri-tert-butylphosphine)palladium(0) (0.6 g) to xylene (600 ml), the mixture was refluxed for 6 hours. After the reaction was finished, the result was extracted and then recrystallized to obtain Int42 (37 g, yield 74%). MS[M+H]+=892

### 3) Synthesis of Compound M31

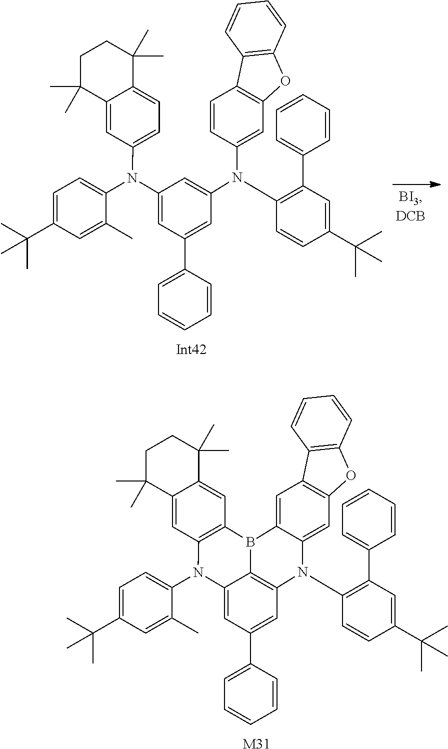

After introducing Int42 (25 g) and boron triiodide (18.7 g) to 1,2-dichlorobenzene (250 ml) under a nitrogen atmosphere, the mixture was stirred for 8 hours at 160° C. After the reaction was finished, the result was extracted and then recrystallized to obtain Compound M31 (7.5 g, yield 30%). MS[M+H]+=900

### Synthesis Example 32. Synthesis of Compound M32

### 1) Synthesis of Int43

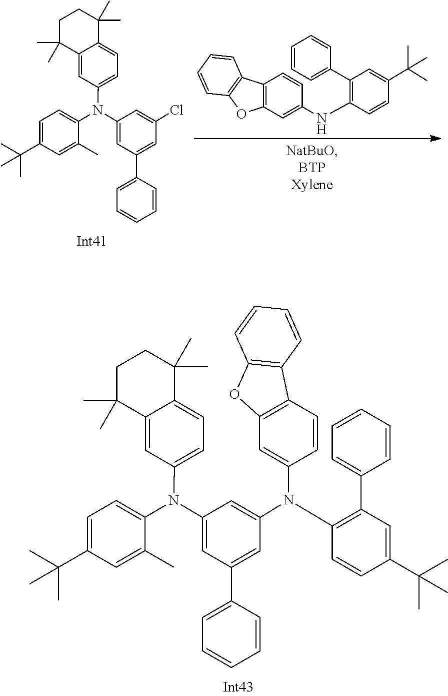

After introducing Int41 (30 g), N-(5-(tert-butyl)-[1,1′-biphenyl]-2-yl)dibenzo[b,d]furan-3-amine (21.9 g), sodium-tert-butoxide (16.1 g) and bis(tri-tert-butylphosphine)palladium(0) (0.6 g) to xylene (600 ml), the mixture was refluxed for 6 hours. After the reaction was finished, the result was extracted and then recrystallized to obtain Int43 (38 g, yield 75%). MS[M+H]+=892

### 3) Synthesis of Compound M32

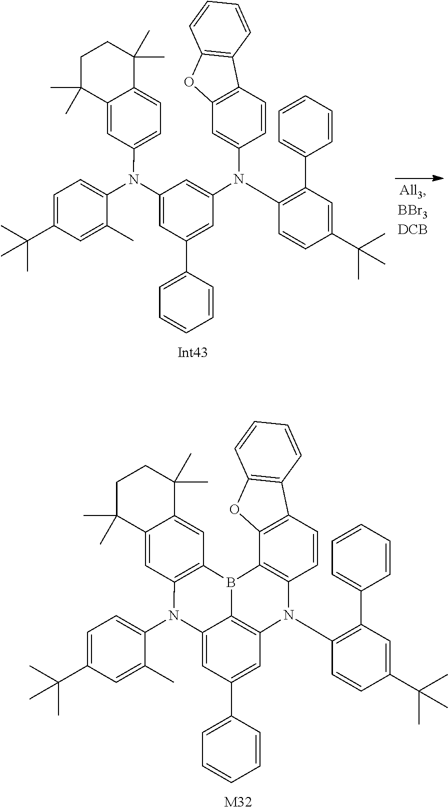

After introducing Int43 (25 g), aluminum iodide (4.6 g) and boron tribromide (21.3 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M32 (7.5 g, yield 30%). MS[M+H]+=990

### Synthesis Example 33. Synthesis of Compound M33

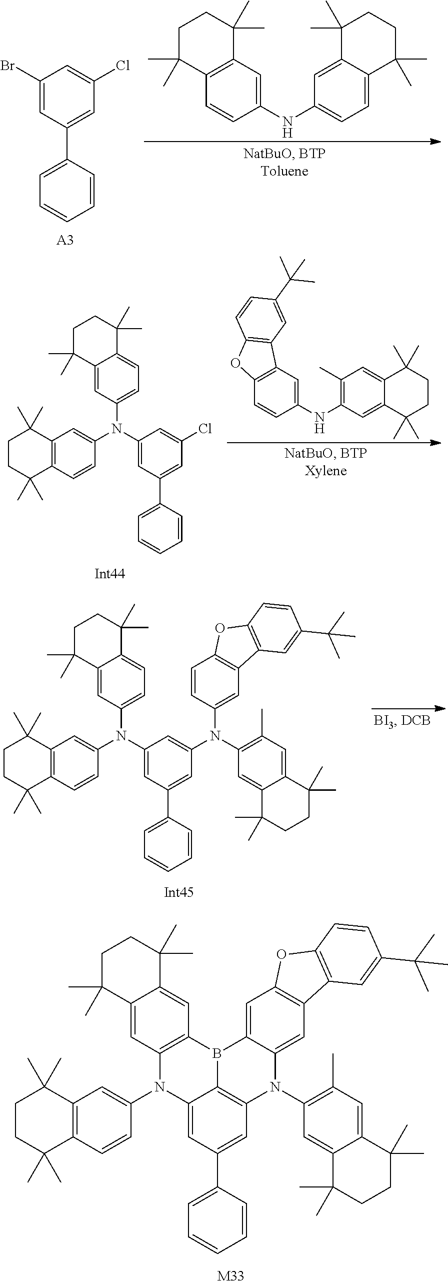

### 1) Synthesis of Int44

Int44 (46 g, yield 71%) was obtained using the same method and equivalents as in Synthesis of Int1 except that A3 and bis(5,5,8,8-tetramethyl-5,6,7,8-tetrahydronaphthalen-2-yl)amine were used. MS[M+H]+=577

### 2) Synthesis of Int45

Int45 (36 g, yield 71%) was obtained using the same method and equivalents as in Synthesis of Int2 except that Int44 and 8-(tert-butyl)-N-(3,5,5,8,8-pentamethyl-5,6,7,8-tetrahydro-naphthalen-2-yl)dibenzo[b,d]furan-2-amine were used. MS[M+H]+=980

### 3) Synthesis of Compound M33

After introducing Int45 (25 g) and boron triiodide (17 g) to 1,2-dichlorobenzene (250 ml) under a nitrogen atmosphere, the mixture was stirred for 8 hours at 160° C. After the reaction was finished, the result was extracted and then recrystallized to obtain Compound M33 (7.6 g, yield 30%). MS[M+H]+=988

### Synthesis Example 34. Synthesis of Compound M34

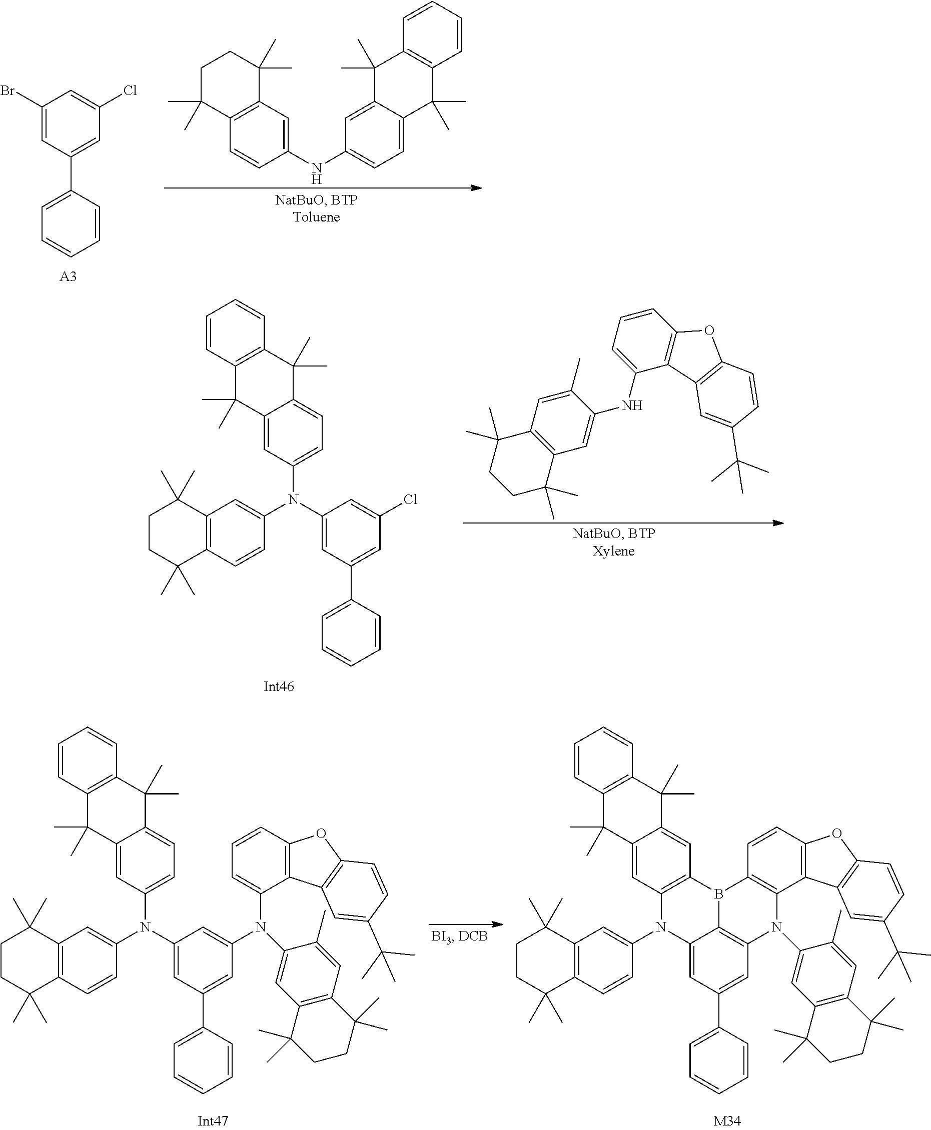

### 1) Synthesis of Int46

Int46 (49 g, yield 70%) was obtained using the same method and equivalents as in Synthesis of Int1 except that A3 and 9,9,10,10-tetramethyl-N-(5,5,8,8-tetramethyl-5,6,7,8-tetrahydronaphthalen-2-yl)-9,10-dihydroanthracen-2-amine were used. MS[M+H]+=625

### 2) Synthesis of Int47

Int47 (37 g, yield 74%) was obtained using the same method and equivalents as in Synthesis of Int2 except that Int46 and 8-(tert-butyl)-N-(3,5,5,8,8-pentamethyl-5,6,7,8-tetrahydronaphthalen-2-yl)dibenzo[b,d]furan-1-amine were used. MS[M+H]+=1042

### 3) Synthesis of Compound M34

After introducing Int47 (25 g) and boron triiodide (16 g) to 1,2-dichlorobenzene (250 ml) under a nitrogen atmosphere, the mixture was stirred for 8 hours at 160° C. After the reaction was finished, the result was extracted and then recrystallized to obtain Compound M34 (7.7 g, yield 31%). MS[M+H]+=1050

### Synthesis Example 35. Synthesis of Compound M35

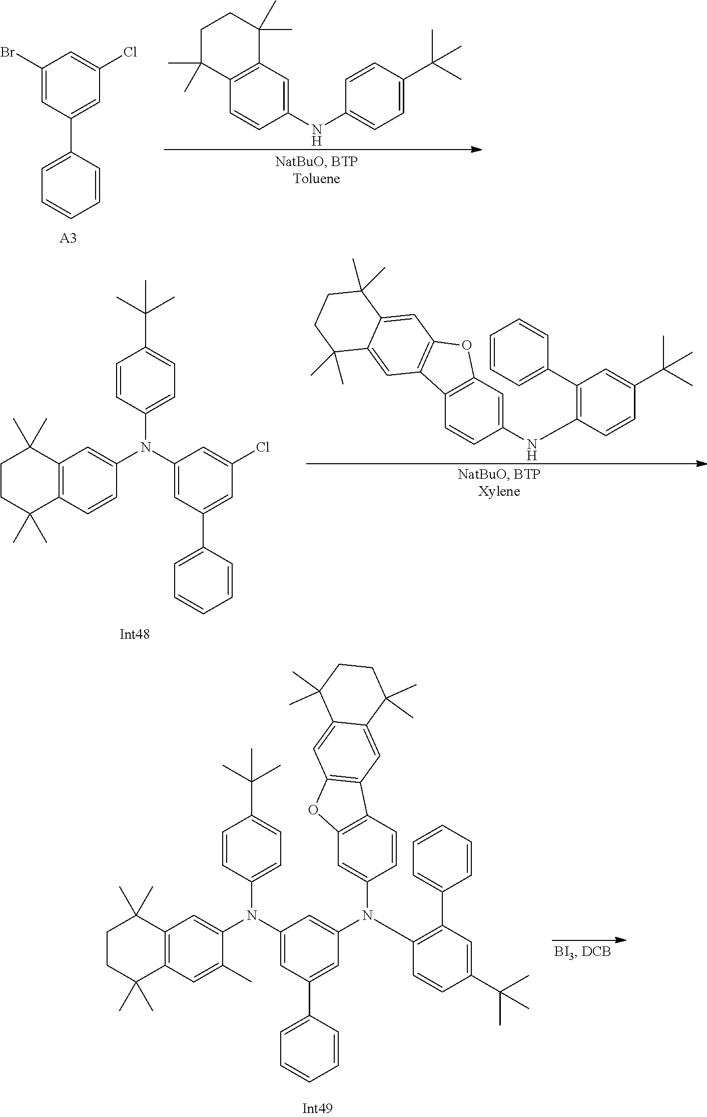

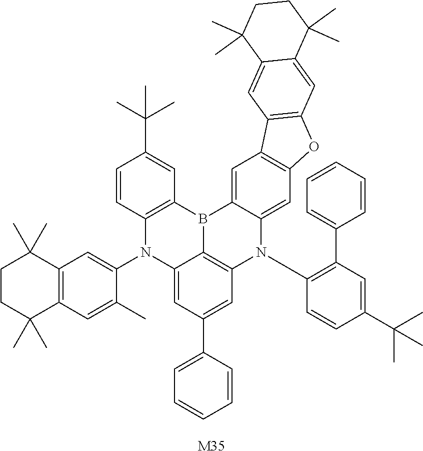

### 1) Synthesis of Int48

Int48 (43 g, yield 73%) was obtained using the same method and equivalents as in Synthesis of Int1 except that A3 and N-(4-(tert-butyl)phenyl)-5,5,8,8-tetramethyl-5,6,7,8-tetrahydronaphthalen-2-amine were used. MS[M+H]+=523

### 2) Synthesis of Int49

Int49 (41 g, yield 71%) was obtained using the same method and equivalents as in Synthesis of Int2 except that Int48 and N-(5-(tert-butyl)-[1,1′-biphenyl]-2-yl)-7,7,10,10-tetramethyl-7,8,9,10-tetrahydronaphthalene[2,3-b]benzofuran-3-amine were used. MS[M+H]+=1002

### 3) Synthesis of Compound M35

After introducing Int49 (25 g) and boron triiodide (16.7 g) to 1,2-dichlorobenzene (250 ml) under a nitrogen atmosphere, the mixture was stirred for 8 hours at 160° C. After the reaction was finished, the result was extracted and then recrystallized to obtain Compound M35 (7.5 g, yield 30%). MS[M+H]+=1010

### Synthesis Example 36. Synthesis of Compound M36

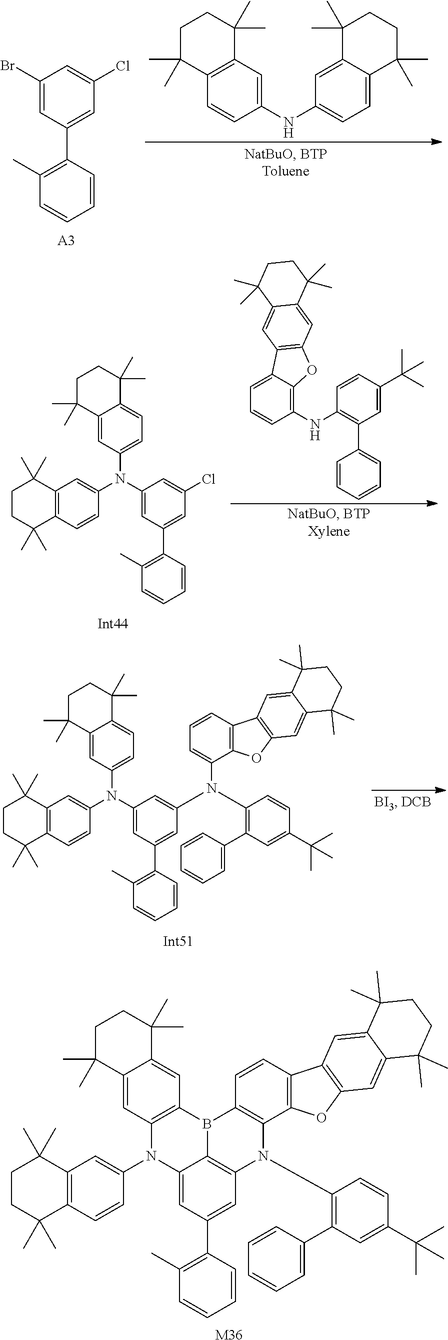

### 1) Synthesis of Int50

Int50 (48 g, yield 73%) was obtained using the same method and equivalents as in Synthesis of Int1 except that 3′-bromo-5′-chloro-2-methyl-1,1′-biphenyl (A4) and bis(5,5,8,8-tetramethyl-5,6,7,8-tetrahydronaphthalen-2-yl)amine were used. MS[M+H]+=591

### 2) Synthesis of Int51

Int51 (40 g, yield 75%) was obtained using the same method and equivalents as in Synthesis of Int2 except that Int50 and N-(5-(tert-butyl)-[1,1′-biphenyl]-2-yl)-7,7,10,10-tetramethyl-7,8,9,10-tetrahydronaphtho[2,3-b]benzofuran-4-amine were used. MS[M+H]+=1056

### 3) Synthesis of Compound M36

After introducing Int51 (25 g) and boron triiodide (15.8 g) to 1,2-dichlorobenzene (250 ml) under a nitrogen atmosphere, the mixture was stirred for 8 hours at 160° C. After the reaction was finished, the result was extracted and then recrystallized to obtain Compound M36 (7.4 g, yield 29%). MS[M+H]+=1064

### Synthesis Example 37. Synthesis of Compound M37

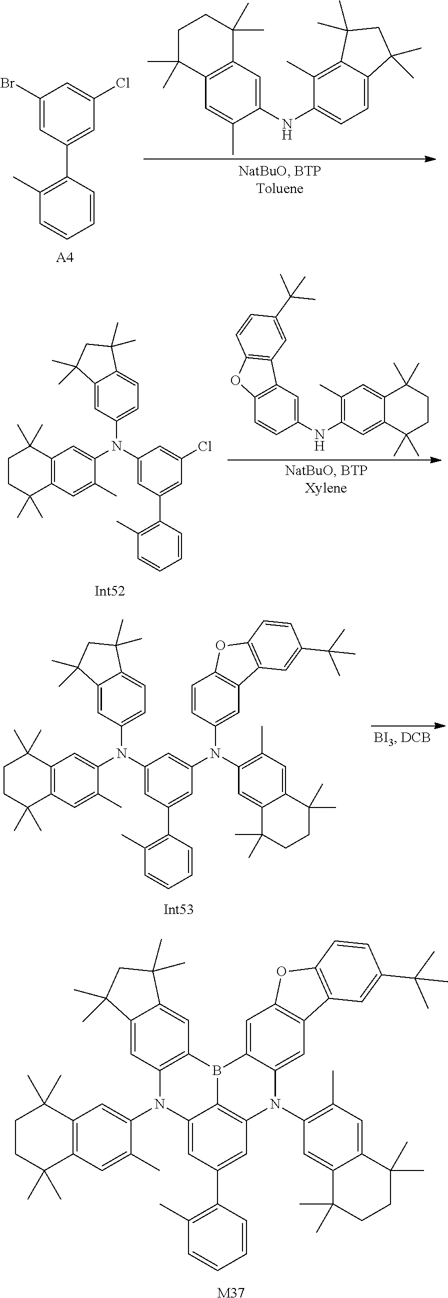

### 1) Synthesis of Int52

Int52 (43 g, yield 70%) was obtained using the same method and equivalents as in Synthesis of Int1 except that A4 and 3,5,5,8,8-pentamethyl-N-(1,1,3,3-tetramethyl-2,3-dihydro-1H-inden-5-yl)-5,6,7,8-tetrahydronaphthalen-2-amine were used. MS[M+H]+=577

### 2) Synthesis of Int53

Int53 (41 g, yield 79%) was obtained using the same method and equivalents as in Synthesis of Int2 except that Int52 and 8-(tert-butyl)-N-(3,5,5,8,8-pentamethyl-5,6,7,8-tetrahydronaphthalen-2-yl)dibenzo[b,d]furan-2-amine were used. MS[M+H]+=994

### 3) Synthesis of Compound M37

After introducing Int53 (25 g) and boron triiodide (16.8 g) to 1,2-dichlorobenzene (250 ml) under a nitrogen atmosphere, the mixture was stirred for 8 hours at 160° C. After the reaction was finished, the result was extracted and then recrystallized to obtain Compound M37 (7.5 g, yield 30%). MS[M+H]+=1002

### Synthesis Example 38. Synthesis of Compound M38

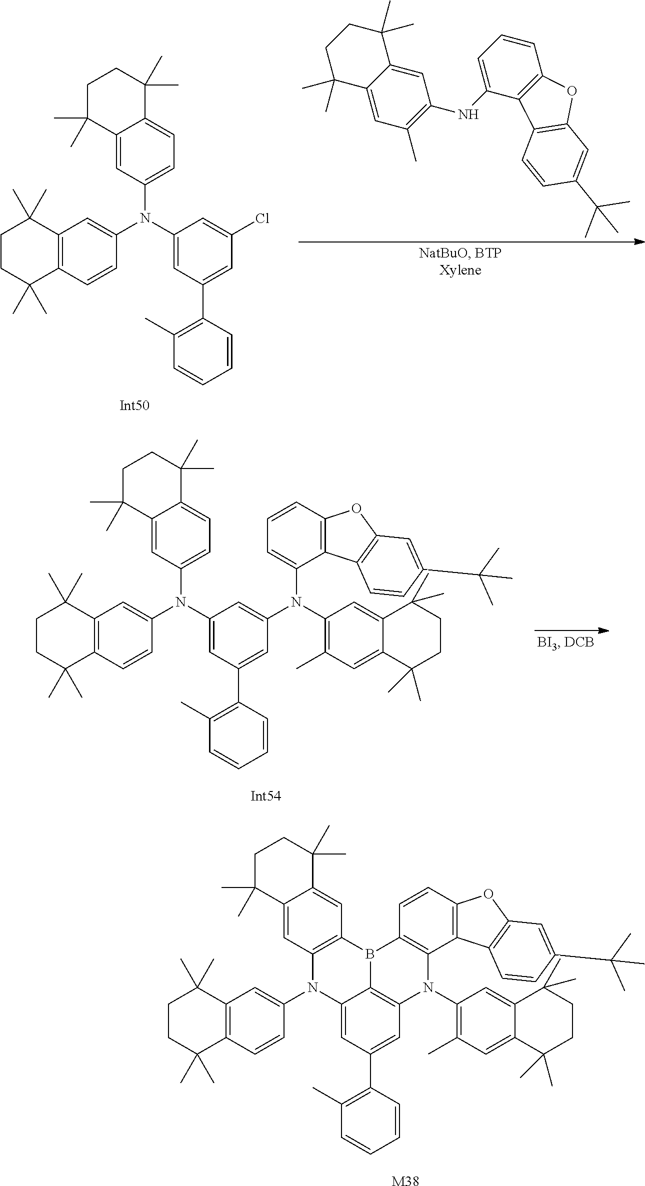

### 1) Synthesis of Int54

Int54 (40 g, yield 77%) was obtained using the same method and equivalents as in Synthesis of Int2 except that Int50 and 7-(tert-butyl)-N-(3,5,5,8,8-pentamethyl-5,6,7,8-tetrahydronaphthalen-2-yl)dibenzo[b,d]furan-2-amine were used. MS[M+H]+=994

### 2) Synthesis of Compound M38

After introducing Int54 (25 g) and boron triiodide (16.8 g) to 1,2-dichlorobenzene (250 ml) under a nitrogen atmosphere, the mixture was stirred for 8 hours at 160° C. After the reaction was finished, the result was extracted and then recrystallized to obtain Compound M38 (7.4 g, yield 29%). MS[M+H]+=1002

### Synthesis Example 39. Synthesis of Compound M39

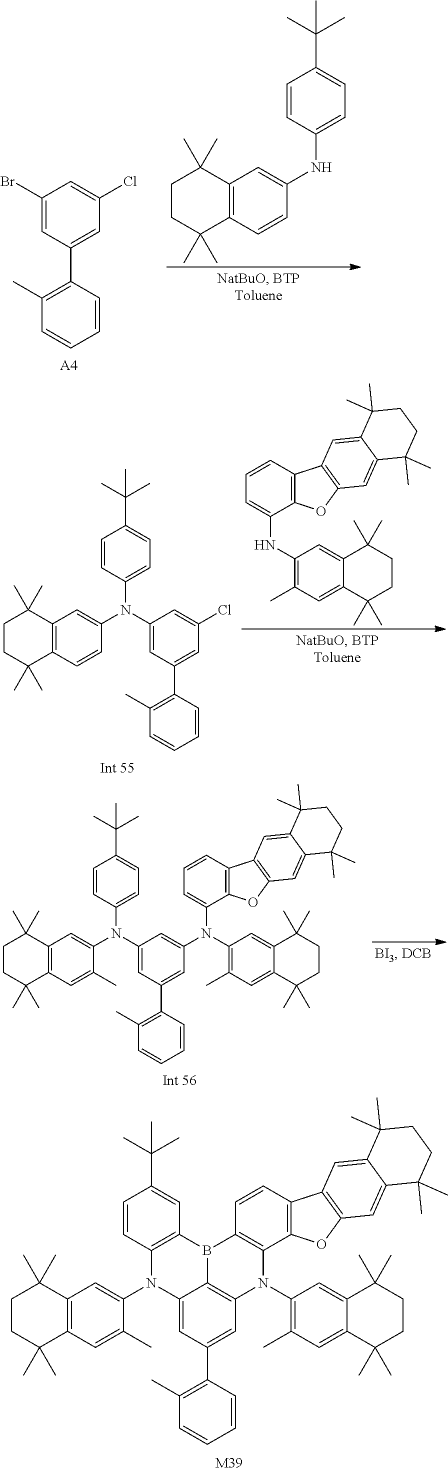

### 1) Synthesis of Int55

Int55 (42 g, yield 74%) was obtained using the same method and equivalents as in Synthesis of Int1 except that A4 and N-(4-(tert-butyl)phenyl)-5,5,8,8-tetramethyl-5,6,7,8-tetrahydronaphthalen-2-amine were used. MS[M+H]+=537

### 2) Synthesis of Int56

Int56 (42 g, yield 75%) was obtained using the same method and equivalents as in Synthesis of Int2 except that Int55 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-4-amine were used. MS[M+H]+=1008

### 3) Synthesis of Compound M39

After introducing Int56 (25 g) and boron triiodide (16.5 g) to 1,2-dichlorobenzene (250 ml) under a nitrogen atmosphere, the mixture was stirred for 8 hours at 160° C. After the reaction was finished, the result was extracted and then recrystallized to obtain Compound M39 (7.6 g, yield 30%). MS[M+H]+=1016

### Synthesis Example 40. Synthesis of Compound M40

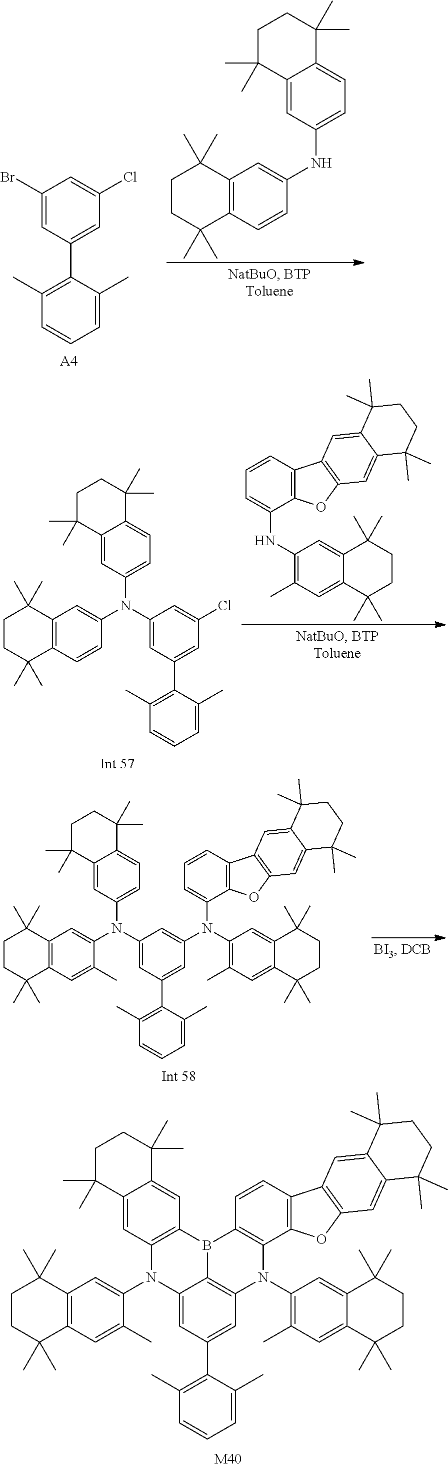

### 1) Synthesis of Int57

Int57 (44 g, yield 72%) was obtained using the same method and equivalents as in Synthesis of Int1 except that 3′-bromo-5′-chloro-2,6-dimethyl-1,1′-biphenyl (A5) and bis(5,5,8,8-tetramethyl-5,6,7,8-tetrahydronaphthalen-2-yl)amine were used. MS[M+H]+=605

### 2) Synthesis of Int58

Int58 (39 g, yield 74%) was obtained using the same method and equivalents as in Synthesis of Int2 except that Int57 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-4-amine were used. MS[M+H]+=1062

### 3) Synthesis of Compound M40

After introducing Int58 (25 g) and boron triiodide (16.5 g) to 1,2-dichlorobenzene (250 ml) under a nitrogen atmosphere, the mixture was stirred for 8 hours at 160° C. After the reaction was finished, the result was extracted and then recrystallized to obtain Compound M40 (7.4 g, yield 29%). MS[M+H]+=1070

### Synthesis Example 41. Synthesis of Compound M41

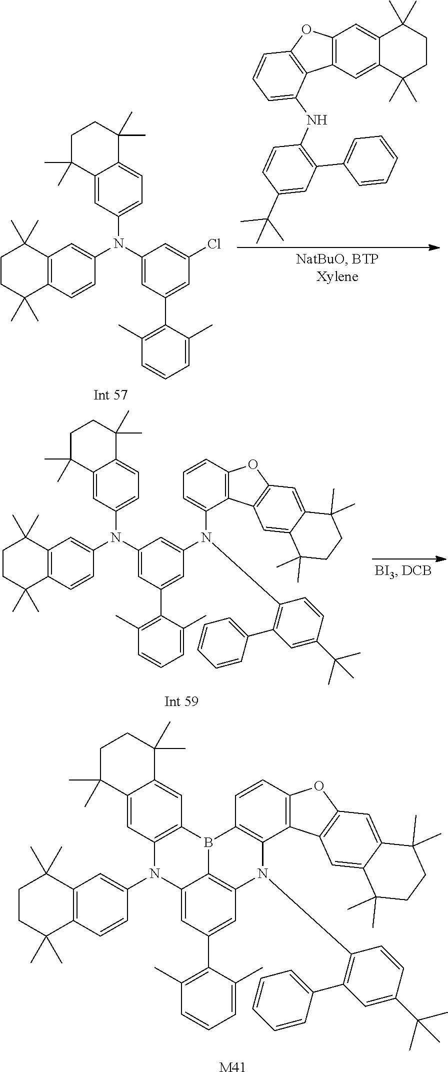

### 1) Synthesis of Int59

Int59 (34 g, yield 64%) was obtained using the same method and equivalents as in Synthesis of Int2 except that Int57 and N-(5-(tert-butyl)-[1,1′-biphenyl]-2-yl)-7,7,10,10-tetramethyl-7,8,9,10-tetrahydronaphtho[2,3-b]benzofuran-1-amine were used. MS[M+H]+=1069

### 2) Synthesis of Compound M41

After introducing Int59 (25 g) and boron triiodide (16.5 g) to 1,2-dichlorobenzene (250 ml) under a nitrogen atmosphere, the mixture was stirred for 8 hours at 160° C. After the reaction was finished, the result was extracted and then recrystallized to obtain Compound M41 (7.5 g, yield 30%). MS[M+H]+=1078

### Synthesis Example 42. Synthesis of Compound M42

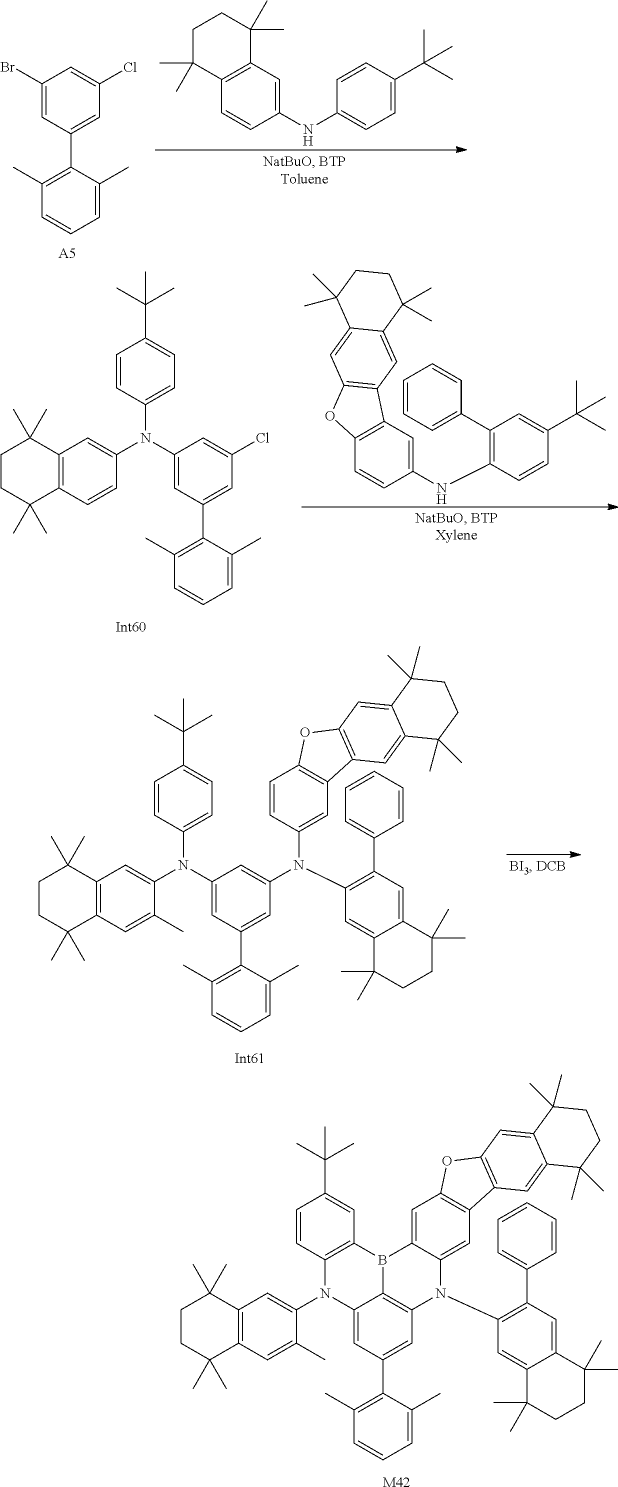

### 1) Synthesis of Int60

Int60 (42 g, yield 75%) was obtained using the same method and equivalents as in Synthesis of Int1 except that A5 and N-(4-(tert-butyl)phenyl)-5,5,8,8-tetramethyl-5,6,7,8-tetrahydronaphthalen-2-amine were used. MS[M+H]+=551

### 2) Synthesis of Int61

Int61 (38 g, yield 68%) was obtained using the same method and equivalents as in Synthesis of Int2 except that Int60 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-2-amine were used. MS[M+H]+=1030

### 3) Synthesis of Compound M42

After introducing Int61 (25 g) and boron triiodide (16.2 g) to 1,2-dichlorobenzene (250 ml) under a nitrogen atmosphere, the mixture was stirred for 8 hours at 160° C. After the reaction was finished, the result was extracted and then recrystallized to obtain Compound M42 (7.5 g, yield 30%). MS[M+H]+=1038

### Synthesis Example 43. Synthesis of Compound M43

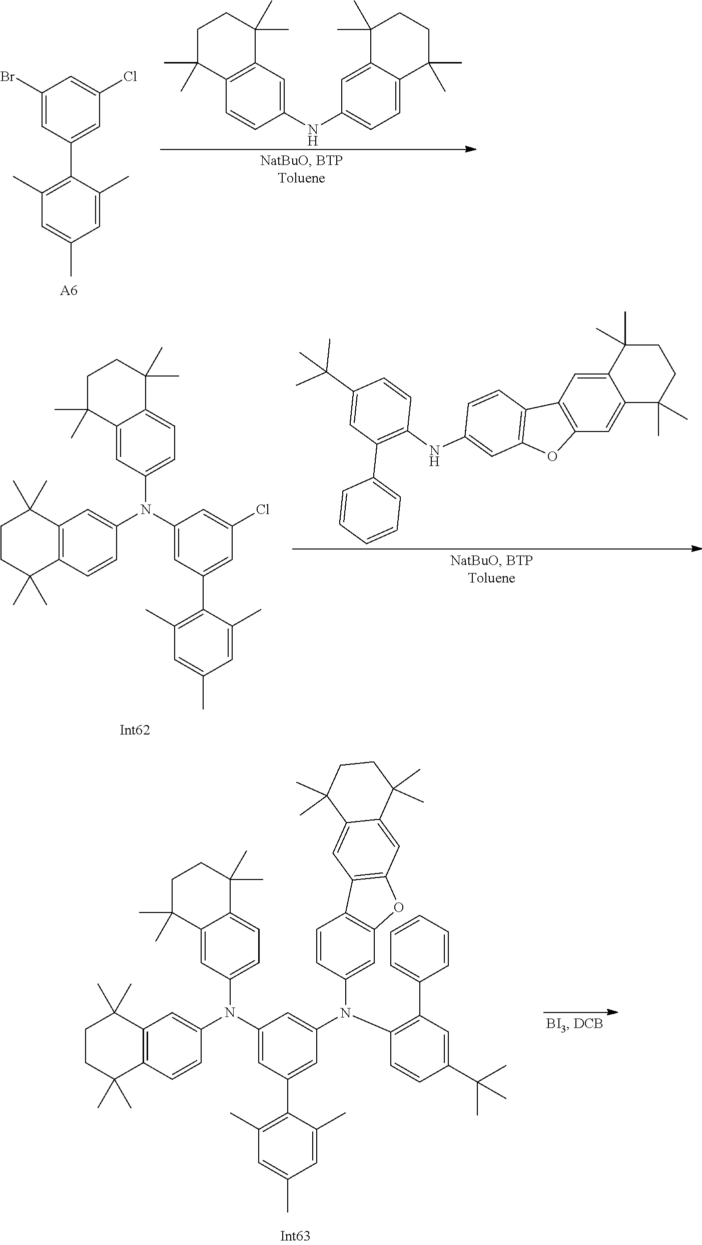

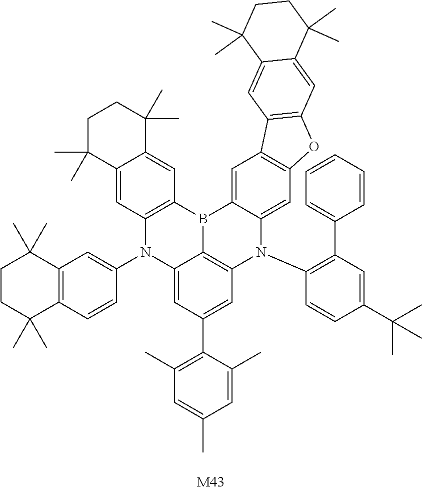

### 1) Synthesis of Int62

Int62 (42 g, yield 70%) was obtained using the same method and equivalents as in Synthesis of Int1 except that 3′-bromo-5′-chloro-2,4,6-trimethyl-1,1′-biphenyl (A6) and bis(5,5,8,8-tetramethyl-5,6,7,8-tetrahydronaphthalen-2-yl)amine were used. MS[M+H]+=619

### 2) Synthesis of Int63

Int63 (39 g, yield 74%) was obtained using the same method and equivalents as in Synthesis of Int2 except that Int62 and N-(5-(tert-butyl)-[1,1′-biphenyl]-2-yl)-7,7,10,10-tetramethyl-7,8,9,10-tetrahydronaphtho[2,3-b]benzofuran-3-amine were used. MS[M+H]+=1084

### 3) Synthesis of Compound M43

After introducing Int63 (25 g) and boron triiodide (15.4 g) to 1,2-dichlorobenzene (250 ml) under a nitrogen atmosphere, the mixture was stirred for 8 hours at 160° C. After the reaction was finished, the result was extracted and then recrystallized to obtain Compound M43 (7.1 g, yield 28%). MS[M+H]+=1092

### Synthesis Example 44. Synthesis of Compound M44

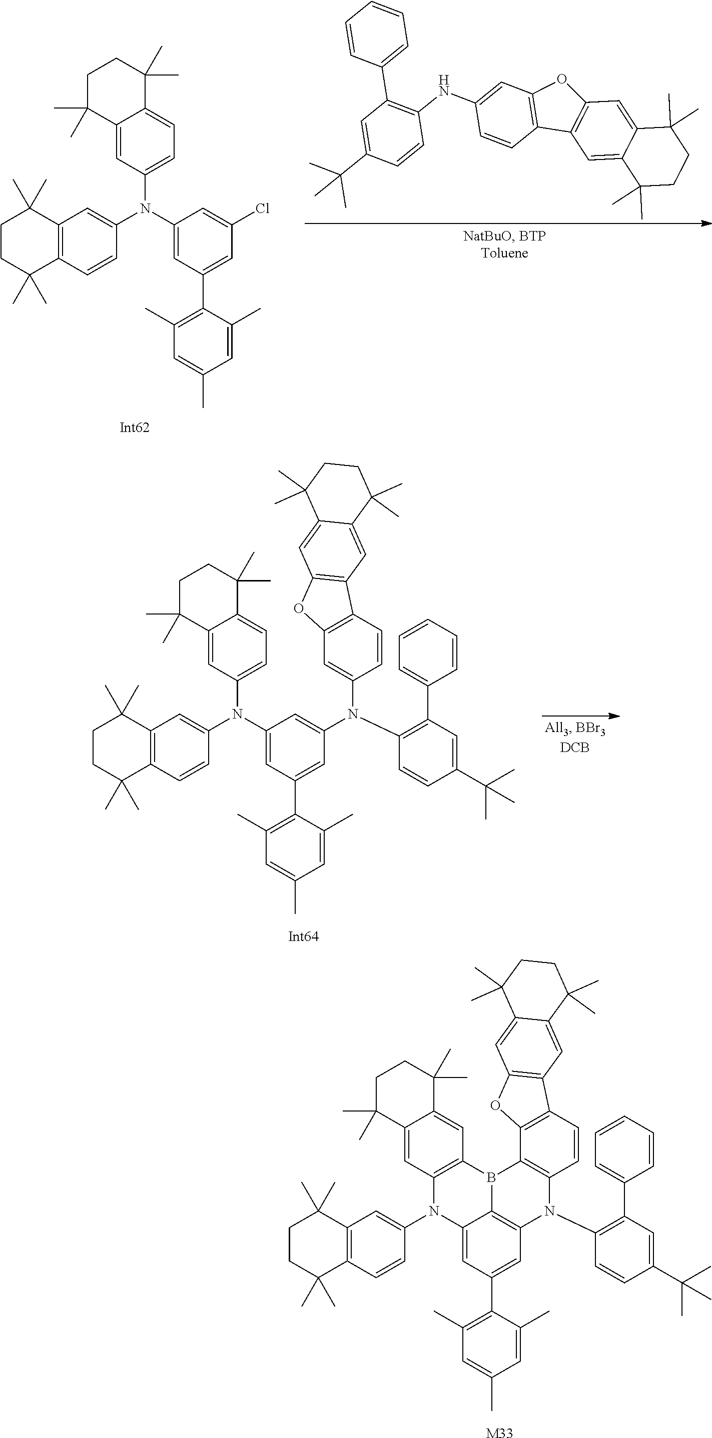

### 1) Synthesis of Int64

Int64 (38 g, yield 73%) was obtained using the same method and equivalents as in Synthesis of Int2 except that Int62 and N-(5-(tert-butyl)-[1,1′-biphenyl]-2-yl)-7,7,10,10-tetramethyl-7,8,9,10-tetrahydronaphtho[2,3-b]benzofuran-3-amine were used. MS[M+H]+=1084

### 2) Synthesis of Compound M44

After introducing Int64 (25 g), aluminum iodide (3.8 g) and boron tribromide (17.5 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M44 (6.9 g, yield 27%). MS[M+H]+=1092

### Synthesis Example 45. Synthesis of Compound M45

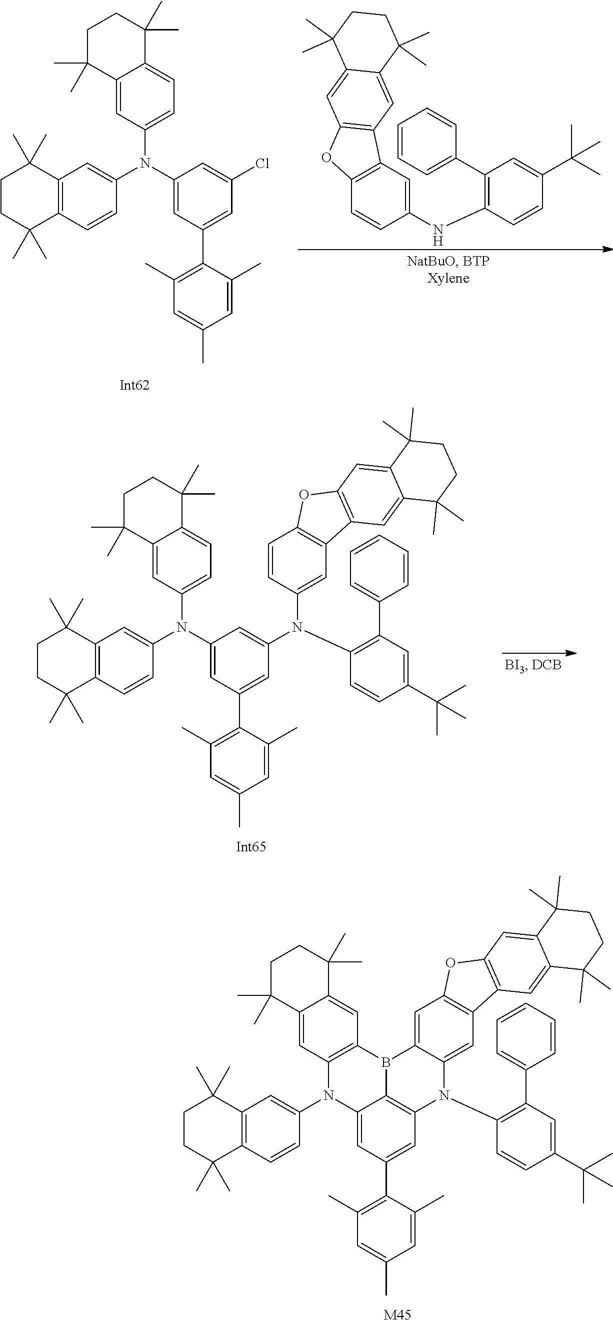

### 1) Synthesis of Int65

Int65 (37 g, yield 72%) was obtained using the same method and equivalents as in Synthesis of Int2 except that Int62 and N-(5-(tert-butyl)-[1,1′-biphenyl]-2-yl)-7,7,10,10-tetramethyl-7,8,9,10-tetrahydronaphtho[2,3-b]benzofuran-2-amine were used. MS[M+H]+=1084

### 2) Synthesis of Compound M45

After introducing Int65 (25 g) and boron triiodide (15.4 g) to 1,2-dichlorobenzene (250 ml) under a nitrogen atmosphere, the mixture was stirred for 8 hours at 160° C. After the reaction was finished, the result was extracted and then recrystallized to obtain Compound M45 (7.1 g, yield 28%). MS[M+H]+=1092

### Synthesis Example 46. Synthesis of Compound M46

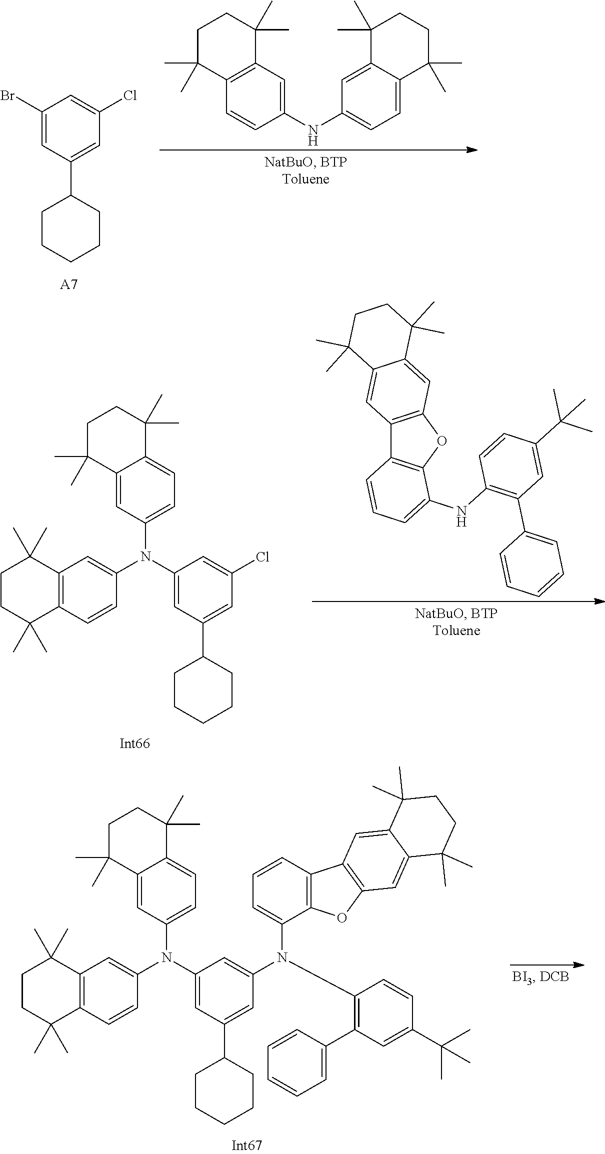

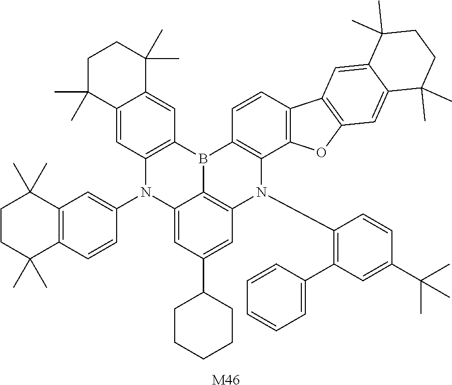

### 1) Synthesis of Int66

Int66 (45 g, yield 70%) was obtained using the same method and equivalents as in Synthesis of Int1 except that 1-bromo-3-chloro-5-cyclohexylbenzene (A7) and bis(5,5,8,8-tetramethyl-5,6,7,8-tetrahydronaphthalen-2-yl)amine were used. MS[M+H]+=583

### 2) Synthesis of Int67

Int67 (41 g, yield 76%) was obtained using the same method and equivalents as in Synthesis of Int2 except that Int66 and N-(5-(tert-butyl)-[1,1′-biphenyl]-2-yl)-7,7,10,10-tetramethyl-7,8,9,10-tetrahydronaphtho[2,3-b]benzofuran-4-amine were used. MS[M+H]+=1048

### 3) Synthesis of Compound M46

After introducing Int67 (25 g) and boron triiodide (15.9 g) to 1,2-dichlorobenzene (250 ml) under a nitrogen atmosphere, the mixture was stirred for 8 hours at 160° C. After the reaction was finished, the result was extracted and then recrystallized to obtain Compound M46 (7.2 g, yield 29%). MS[M+H]+=1056

### Synthesis Example 47. Synthesis of Compound M47

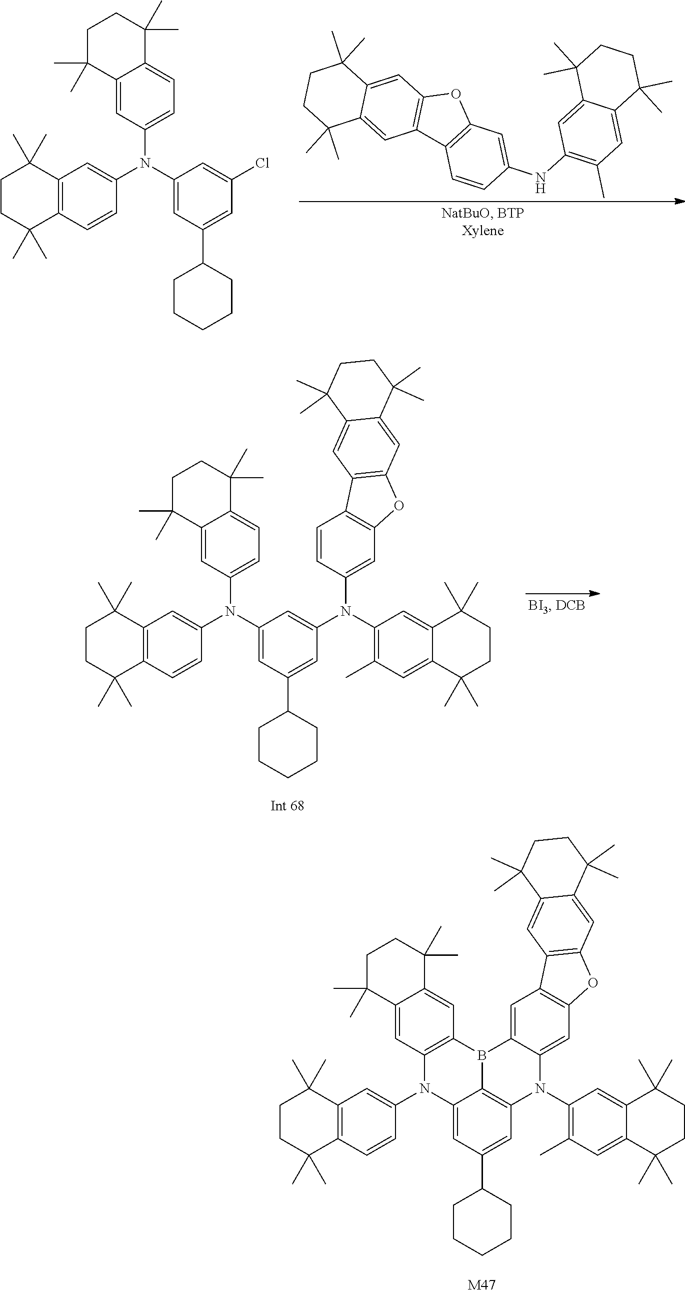

### 1) Synthesis of Int68

Int68 (42 g, yield 78%) was obtained using the same method and equivalents as in Synthesis of Int2 except that Int66 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-3-amine were used. MS[M+H]+=1040

### 2) Synthesis of Compound M47

After introducing Int68 (25 g) and boron triiodide (16 g) to 1,2-dichlorobenzene (250 ml) under a nitrogen atmosphere, the mixture was stirred for 8 hours at 160° C. After the reaction was finished, the result was extracted and then recrystallized to obtain Compound M47 (7.4 g, yield 29%). MS[M+H]+=1048

### Synthesis Example 48. Synthesis of Compound M48

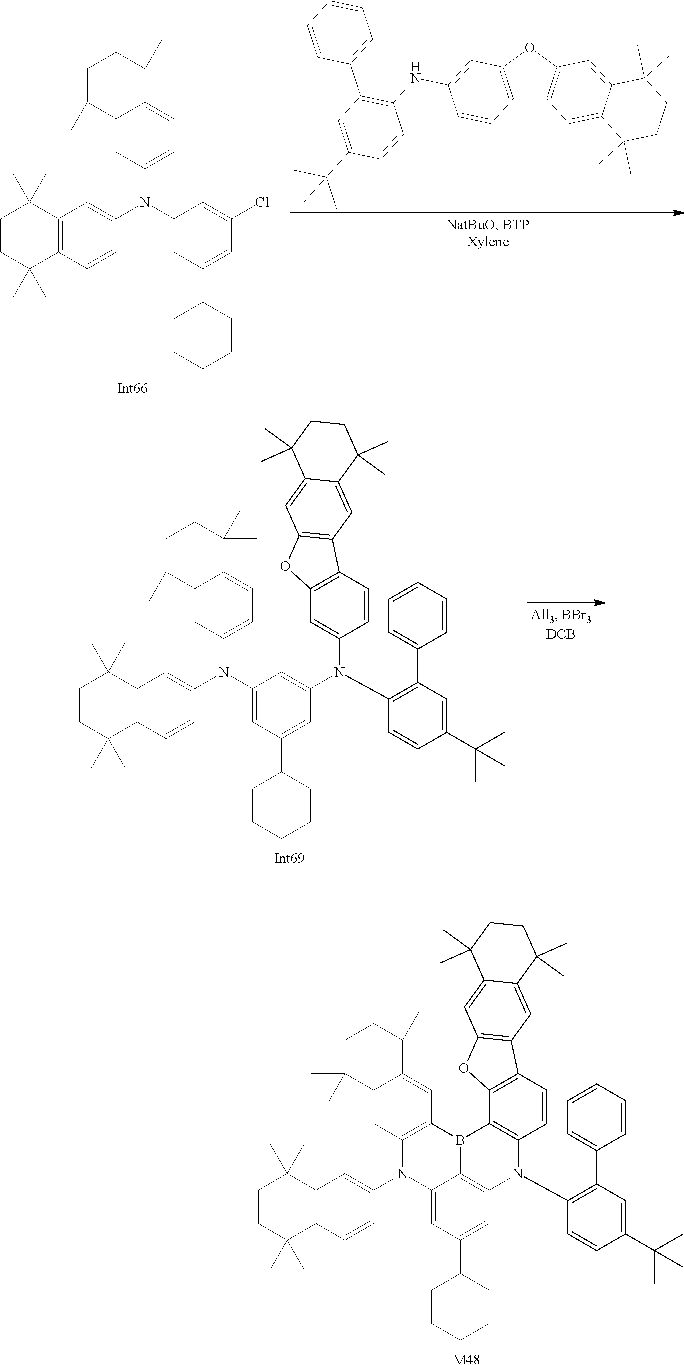

### 1) Synthesis of Int69

Int69 (43 g, yield 80%) was obtained using the same method and equivalents as in Synthesis of Int2 except that Int66 and N-(5-(tert-butyl)-[1,1′-biphenyl]-2-yl)-7,7,10,10-tetramethyl-7,8,9,10-tetrahydronaphtho[2,3-b]benzofuran-3-amine were used. MS[M+H]+=1048

### 2) Synthesis of Compound M48

After introducing Int69 (25 g), aluminum iodide (4.0 g) and boron tribromide (18.2 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M48 (7.2 g, yield 28%). MS[M+H]+=1056

### Synthesis Example 49. Synthesis of Compound M49

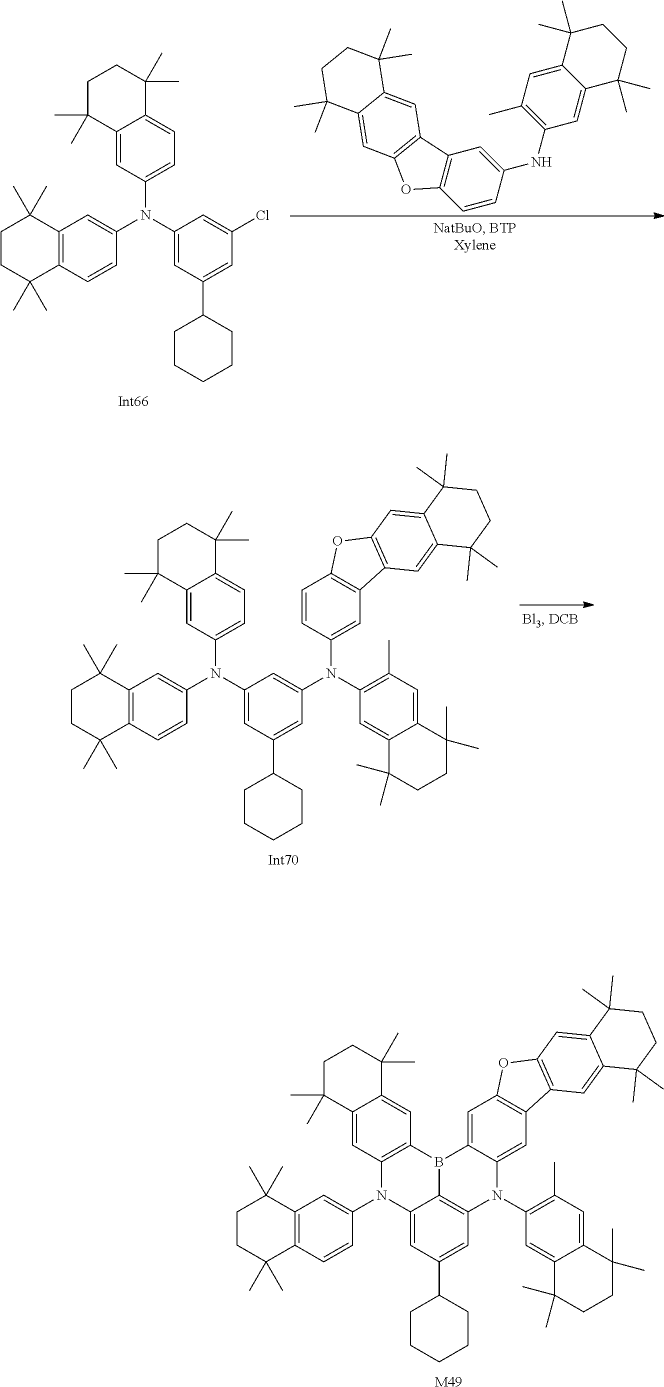

### 1) Synthesis of Int70

Int70 (41 g, yield 77%) was obtained using the same method and equivalents as in Synthesis of Int2 except that Int66 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-2-amine were used. MS[M+H]+=1040

### 2) Synthesis of Compound M49

After introducing Int68 (25 g) and boron triiodide (16 g) to 1,2-dichlorobenzene (250 ml) under a nitrogen atmosphere, the mixture was stirred for 8 hours at 160° C. After the reaction was finished, the result was extracted and then recrystallized to obtain Compound M49 (7.1 g, yield 28%). MS[M+H]+=1048

### Synthesis Example 50. Synthesis of Compound M50

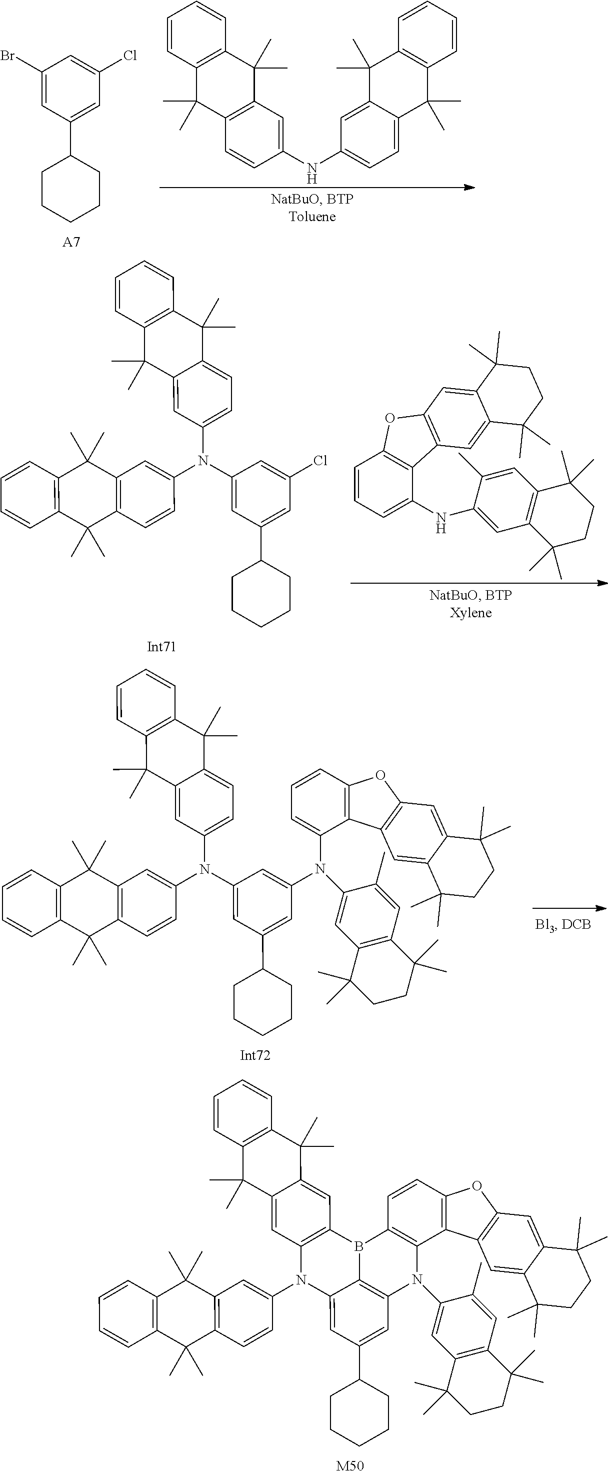

### 1) Synthesis of Int71

Int71 (55 g, yield 74%) was obtained using the same method and equivalents as in Synthesis of Int1 except that A7 and bis(9,9,10,10-tetramethyl-9,10-dihydroanthracen-2-yl)amine were used. MS[M+H]+=679

### 2) Synthesis of Int72

Int72 (34 g, yield 68%) was obtained using the same method and equivalents as in Synthesis of Int2 except that Int71 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-1-amine were used. MS[M+H]+=1136

### 3) Synthesis of Compound M50

After introducing Int72 (25 g) and boron triiodide (14.7 g) to 1,2-dichlorobenzene (250 ml) under a nitrogen atmosphere, the mixture was stirred for 8 hours at 160° C. After the reaction was finished, the result was extracted and then recrystallized to obtain Compound M50 (6.4 g, yield 25%). MS[M+H]+=1144

### Synthesis Example 51. Synthesis of Compound M51

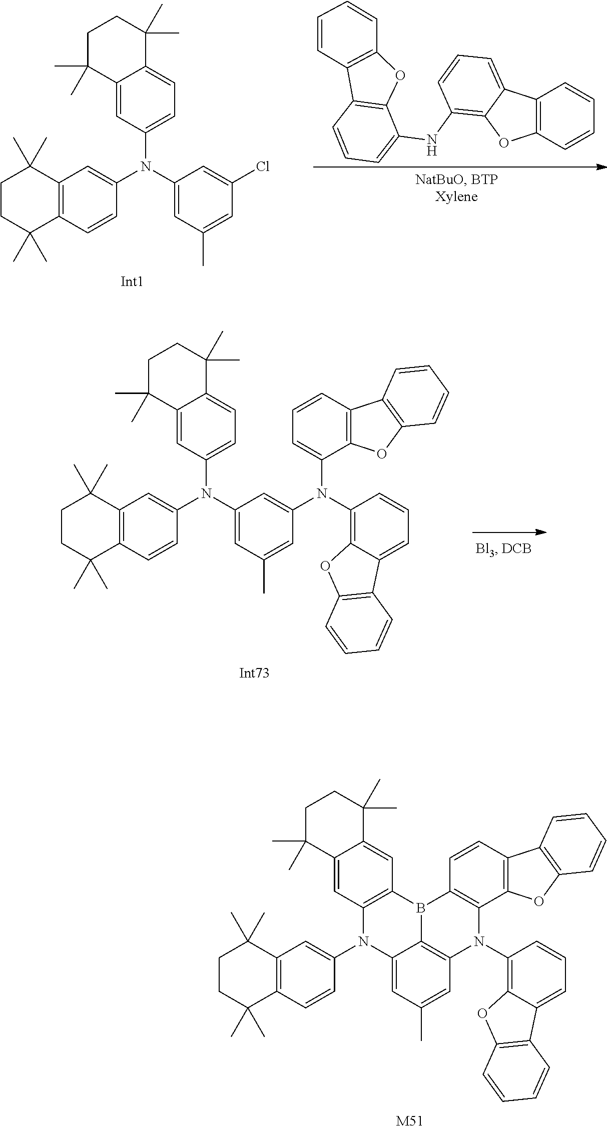 [SMILES: Cc1cc(Cl)cc(N(c2ccc3c(c2)C(C)(C)CCC3(C)C)c2ccc3c(c2)C(C)(C)CCC3(C)C)c1 ; c1ccc2c(c1)oc1c(Nc3cccc4c3oc3ccccc34)cccc12 ; Cc1cc(N(c2ccc3c(c2)C(C)(C)CCC3(C)C)c2ccc3c(c2)C(C)(C)CCC3(C)C)cc(N(c2cccc3c2oc2ccccc23)c2cccc3c2oc2ccccc23)c1 ; Cc1cc2c3c(c1)N(c1cccc4c1oc1ccccc14)c1c(ccc4c1oc1ccccc14)B3c1cc3c(cc1N2c1ccc2c(c1)C(C)(C)CCC2(C)C)C(C)(C)CCC3(C)C ; "M51"]

### 1) Synthesis of Int73

Int73 (35 g, yield 73%) was obtained using the same method and equivalents as in Synthesis of Int2 except that Int1 and bis(dibenzo[b,d]furan-4-yl)amine were used. MS[M+H]+=828

### 2) Synthesis of Compound M51

After introducing Int73 (25 g) and boron triiodide (20.1 g) to 1,2-dichlorobenzene (250 ml) under a nitrogen atmosphere, the mixture was stirred for 8 hours at 160° C. After the reaction was finished, the result was extracted and then recrystallized to obtain Compound M51 (7.4 g, yield 29%). MS[M+H]+=836

### Synthesis Example 52. Synthesis of Compound M52

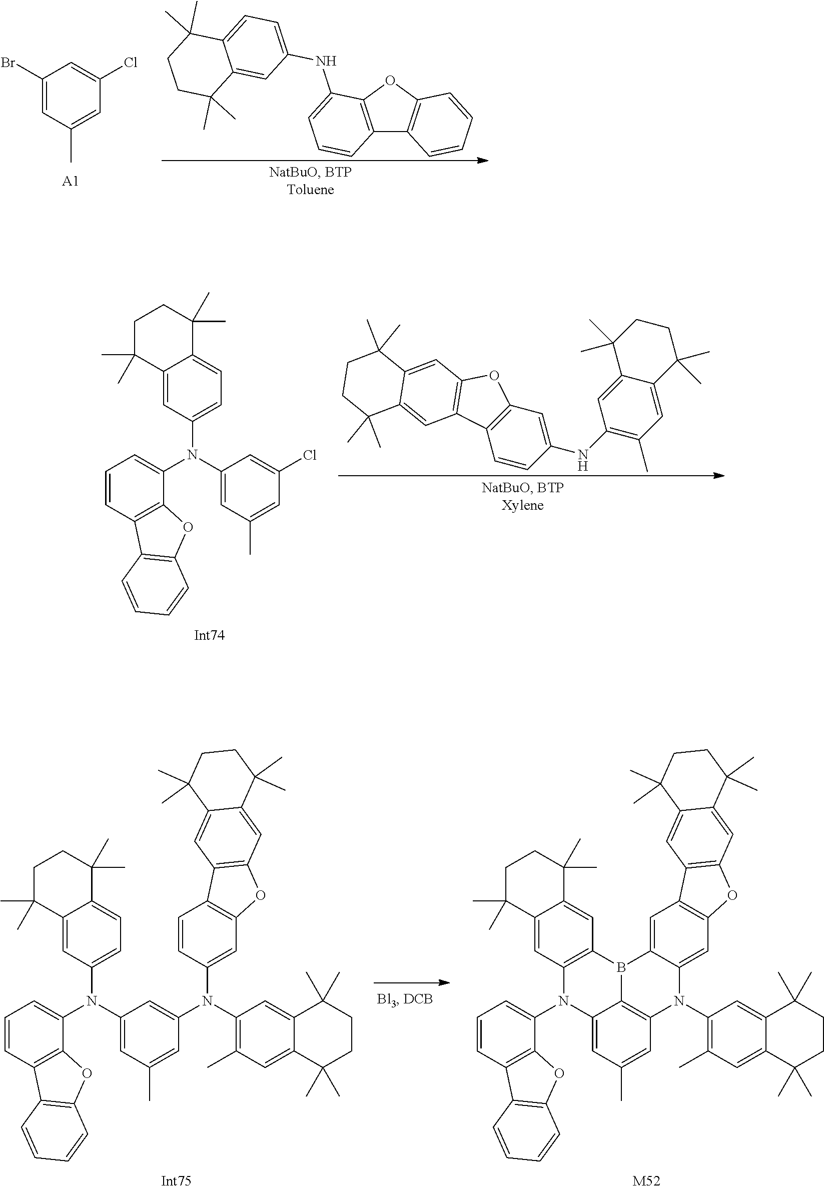

### 1) Synthesis of Int74

Int74 (53 g, yield 73%) was obtained using the same method and equivalents as in Synthesis of Int1 except that A1 and N-(5,5,8,8-tetramethyl-5,6,7,8-tetrahydronaphthalen-2-yl)dibenzo[b,d]furan-4-amine were used. MS[M+H]+=495

### 2) Synthesis of Int75

Int75 (44 g, yield 76%) was obtained using the same method and equivalents as in Synthesis of Int2 except that Int74 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-3-amine were used. MS[M+H]+=952

### 3) Synthesis of Compound M52

After introducing Int75 (25 g) and boron triiodide (17.5 g) to 1,2-dichlorobenzene (250 ml) under a nitrogen atmosphere, the mixture was stirred for 8 hours at 160° C. After the reaction was finished, the result was extracted and then recrystallized to obtain Compound M52 (7.1 g, yield 28%). MS[M+H]+=960

### Synthesis Example 53. Synthesis of Compound M53

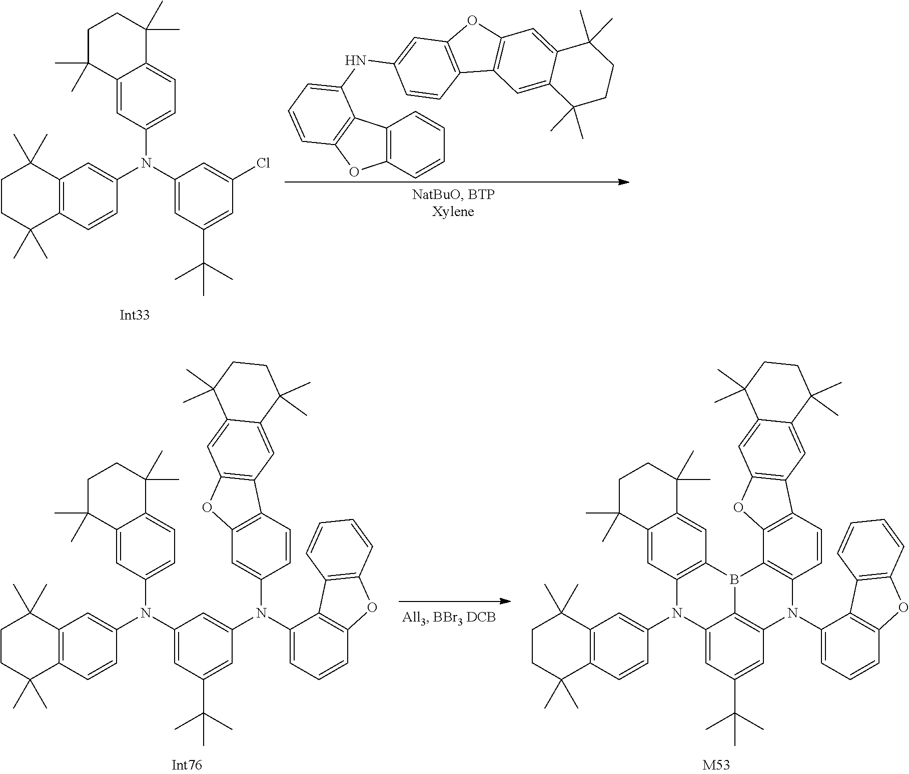

### 1) Synthesis of Int76

Int76 (38 g, yield 72%) was obtained using the same method and equivalents as in Synthesis of Int2 except that Int33 and N-(dibenzo[b,d]furan-1-yl)-7,7,10,10-tetramethyl-7,8,9,10-tetrahydronaphtho[2,3-b]benzofuran-3-amine were used. MS[M+H]+=980

### 2) Synthesis of Compound M53

After introducing Int76 (25 g), aluminum iodide (4.2 g) and boron tribromide (19.4 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M53 (7.3 g, yield 29%). MS[M+H]+=988

### Synthesis Example 54. Synthesis of Compound M54

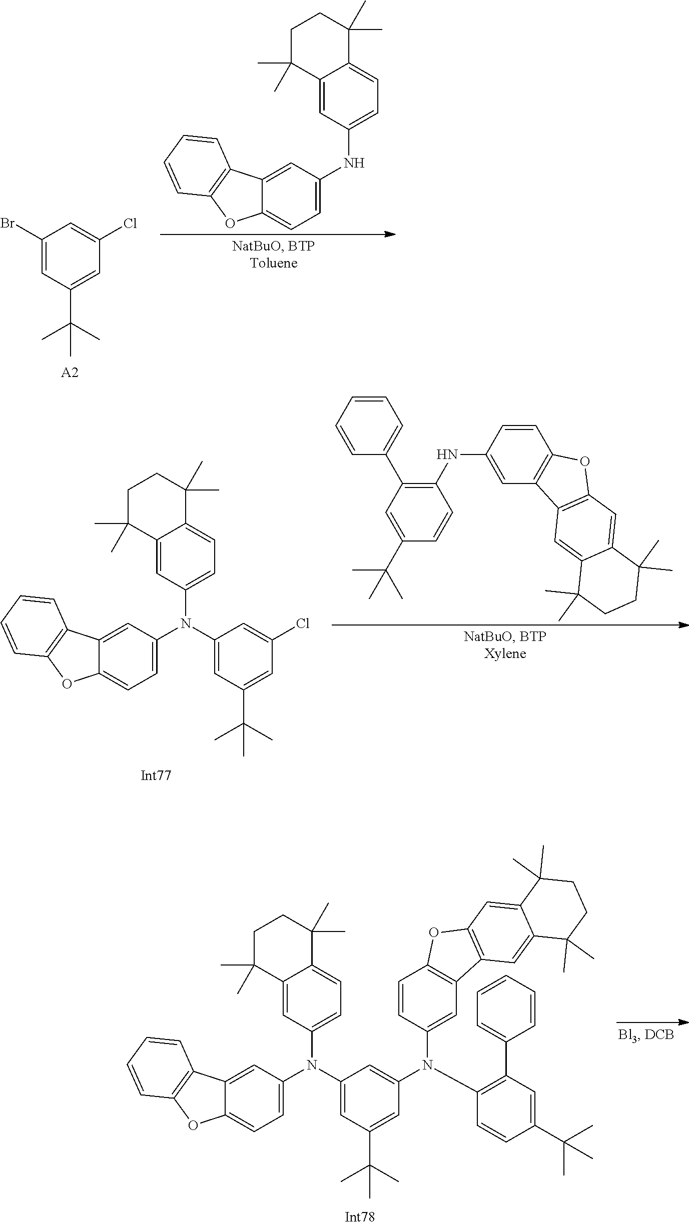

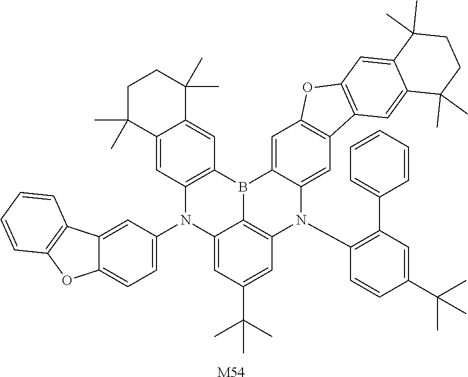

### 1) Synthesis of Int77

Int77 (51 g, yield 78%) was obtained using the same method and equivalents as in Synthesis of Int1 except that A2 and N-(5,5,8,8-tetramethyl-5,6,7,8-tetrahydronaphthalen-2-yl)dibenzo[b,d]furan-2-amine were used. MS[M+H]+=537

### 2) Synthesis of Int78

Int78 (41 g, yield 73%) was obtained using the same method and equivalents as in Synthesis of Int2 except that Int77 and N-(5-(tert-butyl)-[1,1′-biphenyl]-2-yl)-7,7,10,10-tetramethyl-7,8,9,10-tetrahydronaphtho[2,3-b]benzofuran-2-amine were used. MS[M+H]+=1002

### 3) Synthesis of Compound M54

After introducing Int78 (25 g) and boron triiodide (16.6 g) to 1,2-dichlorobenzene (250 ml) under a nitrogen atmosphere, the mixture was stirred for 8 hours at 160° C. After the reaction was finished, the result was extracted and then recrystallized to obtain Compound M54 (7.5 g, yield 30%). MS[M+H]+=1010

### Synthesis Example 55. Synthesis of Compound M55

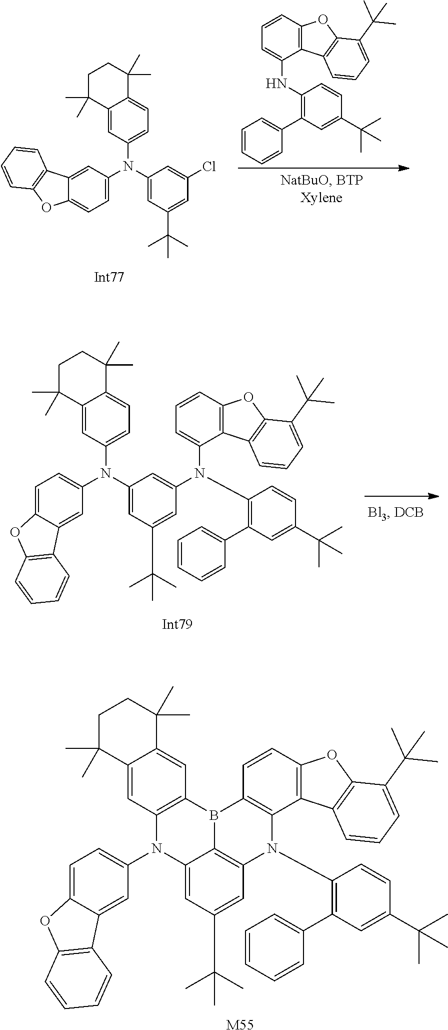

### 1) Synthesis of Int79

Int79 (41 g, yield 77%) was obtained using the same method and equivalents as in Synthesis of Int2 except that Int77 and 6-(tert-butyl)-N-(5-(tert-butyl)-[1,1′-biphenyl]-2-yl)dibenzo[b,d]furan-1-amine were used. MS[M+H]+=948

### 2) Synthesis of Compound M55

After introducing Int79 (25 g) and boron triiodide (17.6 g) to 1,2-dichlorobenzene (250 ml) under a nitrogen atmosphere, the mixture was stirred for 8 hours at 160° C. After the reaction was finished, the result was extracted and then recrystallized to obtain Compound M55 (7.6 g, yield 30%). MS[M+H]+=956

### Synthesis Example 56. Synthesis of Compound M56

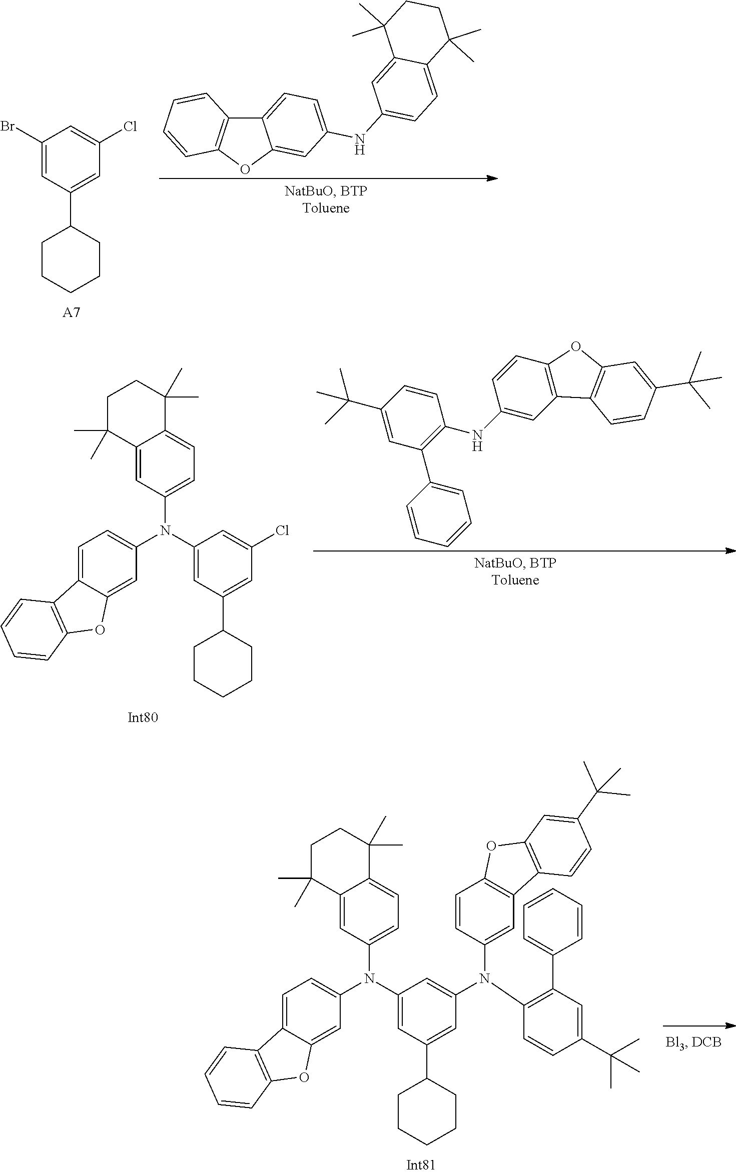

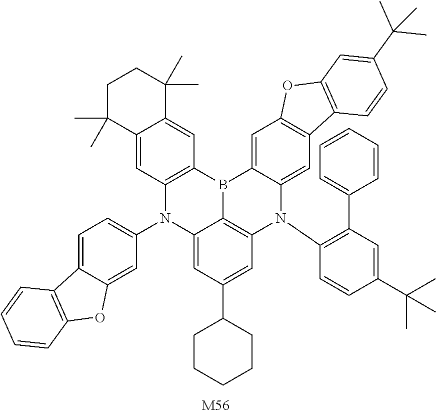

### 1) Synthesis of Int80

Int80 (44 g, yield 71%) was obtained using the same method and equivalents as in Synthesis of Int1 except that A7 and N-(5,5,8,8-tetramethyl-5,6,7,8-tetrahydronaphthalen-2-yl)dibenzo[b,d]furan-3-amine were used. MS[M+H]+=563

### 2) Synthesis of Int81

Int81 (40 g, yield 77%) was obtained using the same method and equivalents as in Synthesis of Int2 except that Int80 and 7-(tert-butyl)-N-(5-(tert-butyl)-[1,1′-biphenyl]-2-yl)dibenzo[b,d]furan-2-amine were used. MS[M+H]+=974

### 3) Synthesis of Compound M56

After introducing Int81 (25 g) and boron triiodide (17.1 g) to 1,2-dichlorobenzene (250 ml) under a nitrogen atmosphere, the mixture was stirred for 8 hours at 160° C. After the reaction was finished, the result was extracted and then recrystallized to obtain Compound M56 (7.6 g, yield 30%). MS[M+H]+=982

### Synthesis Example 57. Synthesis of Compound M57

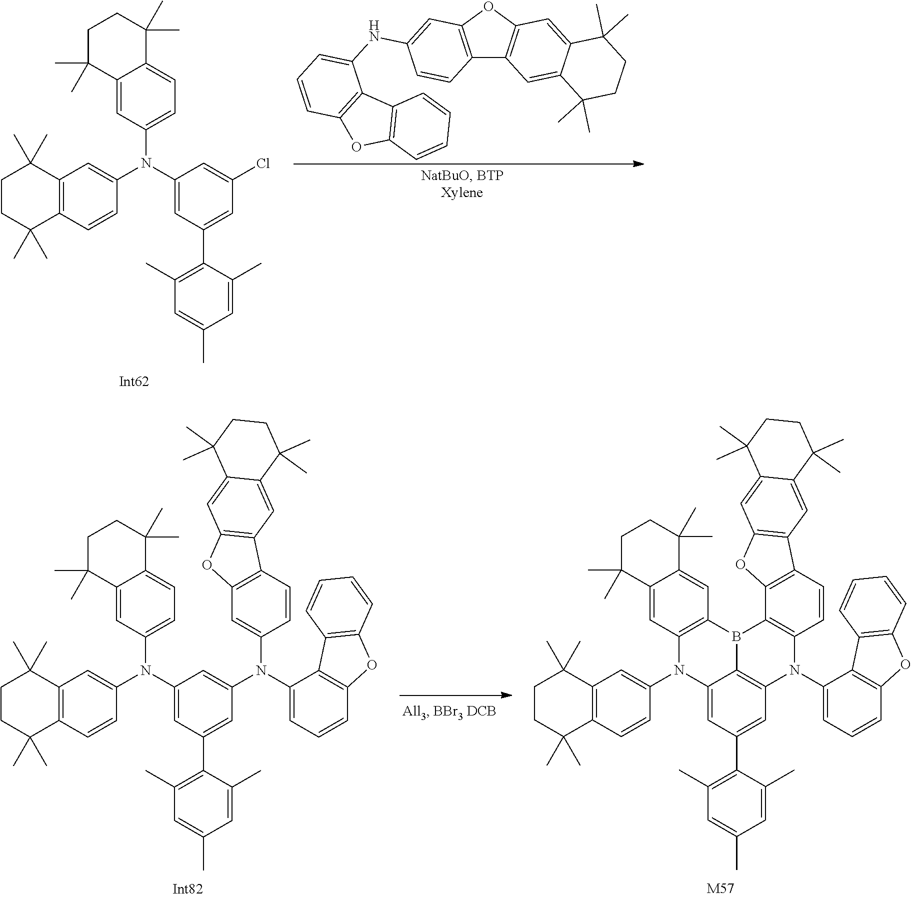

### 1) Synthesis of Int82

Int82 (38 g, yield 75%) was obtained using the same method and equivalents as in Synthesis of Int2 except that Int62 and N-(dibenzo[b,d]furan-1-yl)-7,7,10,10-tetramethyl-7,8,9,10-tetrahydronaphtho[2,3-b]benzofuran-3-amine were used. MS[M+H]+=1042

### 2) Synthesis of Compound M57

After introducing Int82 (25 g), aluminum iodide (3.9 g) and boron tribromide (18.2 ml) to 1,2-dichlorobenzene (250 ml) under a nitrogen atmosphere, the mixture was stirred for 8 hours at 160° C. After the reaction was finished, the result was extracted, then passed through a column and then recrystallized to obtain Compound M57 (7.5 g, yield 30%). MS[M+H]+=1050

### Synthesis Example 58. Synthesis of Compound M58

### 1) Synthesis of Int83

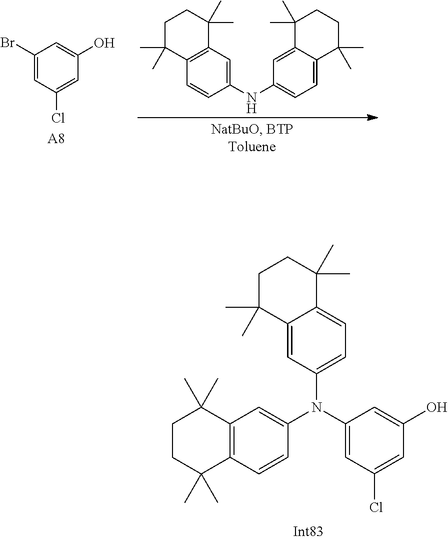

After introducing 3-bromo-5-chlorophenol (A8) (30 g), bis(5,5,8,8-tetramethyl-5,6,7,8-tetrahydronaphthalen-2-yl)amine (56.3 g), sodium-tert-butoxide (41.7 g) and bis(tri-tert-butylphosphine)palladium(0) (1.5 g) to toluene (600 ml), the mixture was refluxed for 1 hour. After the reaction was finished, the result was extracted, and then recrystallized to obtain Int83 (54 g, yield 72%). MS[M+H]+=517

### 2) Synthesis of Int84

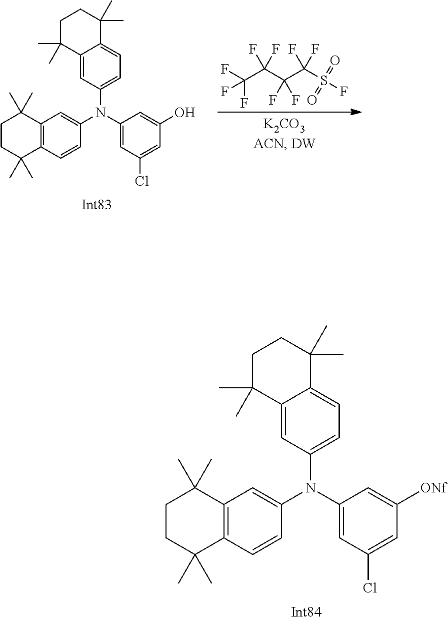

After introducing Int83 (40 g), 1,1,2,2,3,3,4,4,4-nonafluorobutane-1-sulfonyl fluoride (20.9 ml) and potassium carbonate (32.1 g) to acetonitrile (400 ml) and water (200 ml), the mixture was reacted for 2 hours. After the reaction was finished, the result was extracted, and then the solution was removed to obtain Int84 (56 g, yield 91%). MS[M+H]+=799

### 3) Synthesis of Int85

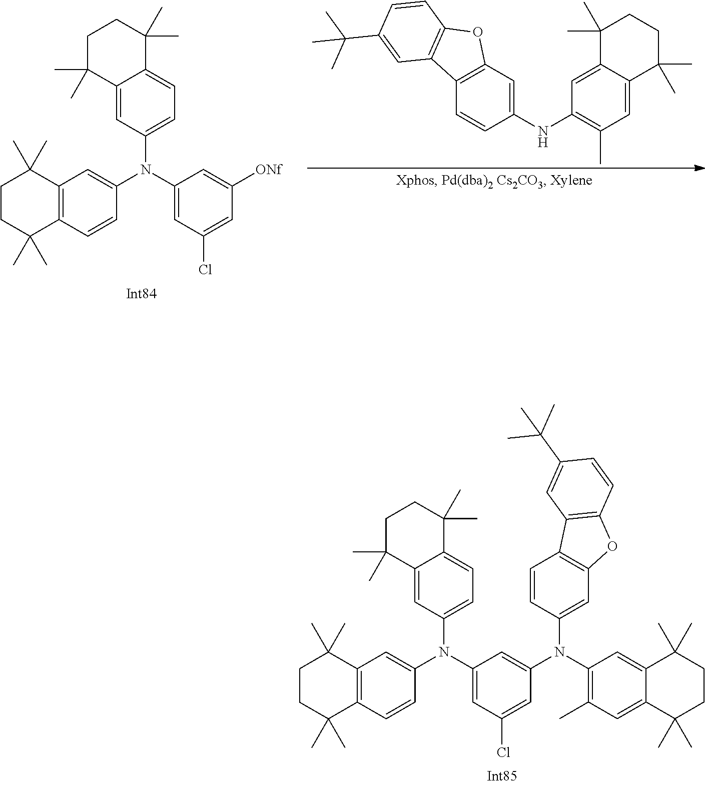

After introducing Int84 (40 g), 8-(tert-butyl)-N-(3,5,5,8,8-pentamethyl-5,6,7,8-tetrahydronaphthalen-2-yl)-dibenzo[b,d]furan-3-amine (22.9 g), Pd(dba)₂ (0.86 g), Xphos (1.43 g) and cesium carbonate (49 g) to xylene (500 ml) under a nitrogen atmosphere, the mixture was stirred for 24 hours under reflux. After the reaction was finished, the result was extracted and then recrystallized to obtain Int85 (36 g, yield 77%). MS[M+H]+=938

### 4)Synthesis of Int86

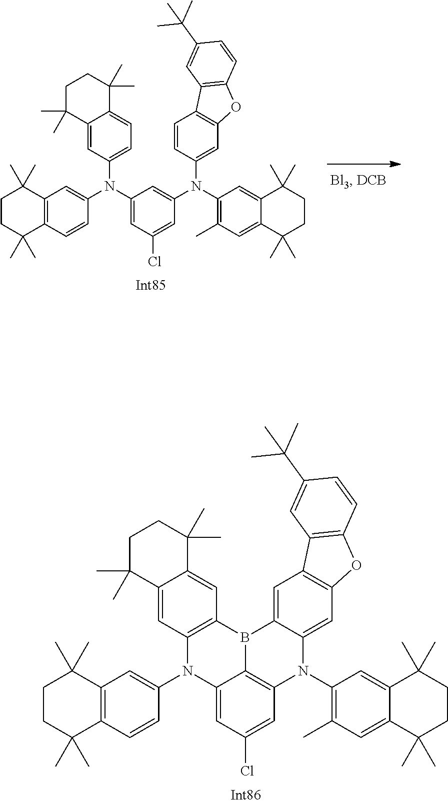 [SMILES: Cc1cc2c(cc1N(c1cc(Cl)cc(N(c3ccc4c(c3)C(C)(C)CCC4(C)C)c3ccc4c(c3)C(C)(C)CCC4(C)C)c1)c1ccc3c(c1)oc1ccc(C(C)(C)C)cc13)C(C)(C)CCC2(C)C ; Cc1cc2c(cc1N1c3cc4oc5ccc(C(C)(C)C)cc5c4cc3B3c4cc5c(cc4N(c4ccc6c(c4)C(C)(C)CCC6(C)C)c4cc(Cl)cc1c43)C(C)(C)CCC5(C)C)C(C)(C)CCC2(C)C]

After introducing Int85 (25 g) and boron triiodide (17.8 g) to 1,2-dichlorobenzene (250 ml), the mixture was stirred for 4 hours at 160° C. After the reaction was finished, the result was extracted and then recrystallized to obtain Int86 (7.2 g, yield 29%). MS[M+H]+=946

### 5) Synthesis of Compound M58

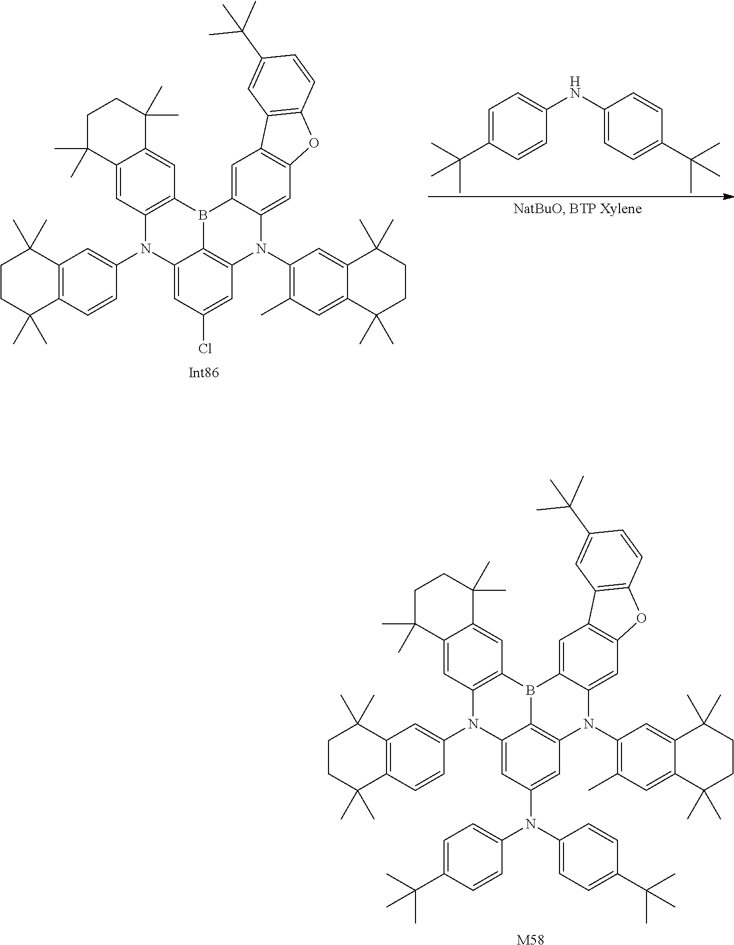 [SMILES: Cc1cc2c(cc1N1c3cc4oc5ccc(C(C)(C)C)cc5c4cc3B3c4cc5c(cc4N(c4ccc6c(c4)C(C)(C)CCC6(C)C)c4cc(Cl)cc1c43)C(C)(C)CCC5(C)C)C(C)(C)CCC2(C)C ; CC(C)(C)c1ccc(Nc2ccc(C(C)(C)C)cc2)cc1 ; Cc1cc2c(cc1N1c3cc4oc5ccc(C(C)(C)C)cc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C ; "M58"]

After introducing Int86 (7 g), bis(4-(tert-butyl)phenyl)amine (2.1 g), sodium-tert-butoxide (2.1 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M58 (6 g, yield 68%). MS[M+H]+=1191

### Synthesis Example 59. Synthesis of Compound M59

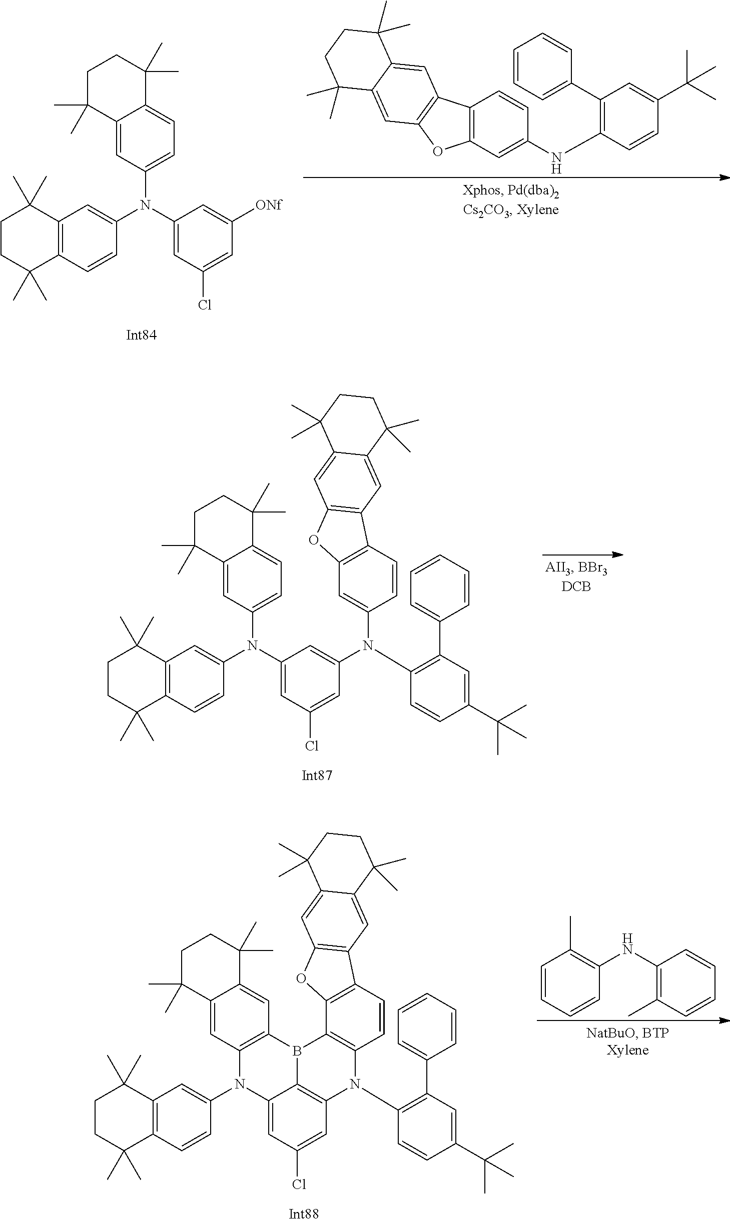

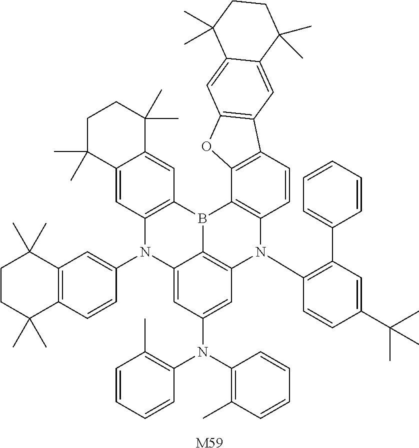

### 1) Synthesis of Int87

Int87 (36 g, yield 77%) was obtained using the same method and equivalents as in Synthesis of Int85 except that Int84 and N-(5-(tert-butyl)-[1,1′-biphenyl]-2-yl)-7,7,10,10-tetramethyl-7,8,9,10-tetrahydronaphtho[2,3-b]benzofuran-3-amine were used under a nitrogen atmosphere. MS[M+H]+=1000

### 2) Synthesis of Int88

After introducing Int87 (25 g), aluminum iodide (4.1 g) and boron tribromide (18.9 ml) to 1,2-dichlorobenzene (250 ml), the mixture was stirred for 8 hours at 160° C. After the reaction was finished, the result was extracted, then passed through a column and then recrystallized to obtain Int88 (7.2 g, yield 29%). MS[M+H]+=1008

### 3) Synthesis of Compound M59

After introducing Int88 (7 g), di-o-tolylamine (1.4 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M59 (6.2 g, yield 76%). MS[M+H]+=1169

### Synthesis Example 60. Synthesis of Compound M60

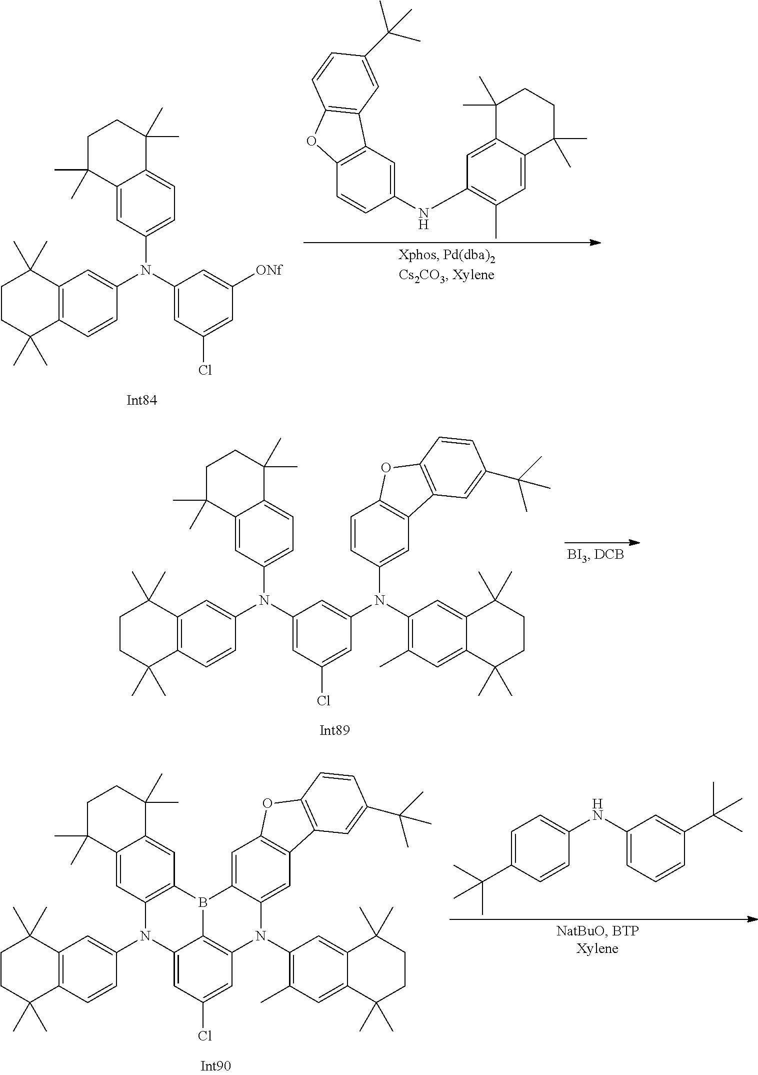

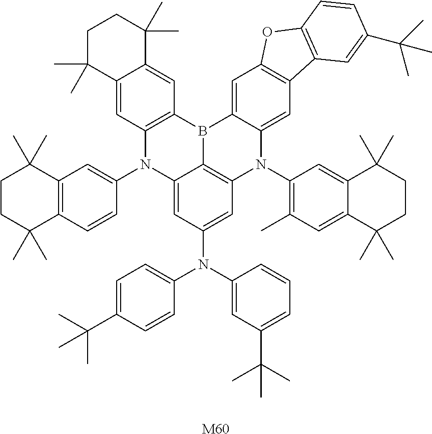 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7cccc(C(C)(C)C)c7)cc1c53)C(C)(C)CCC6(C)C)oc1ccc(C(C)(C)C)cc14)C(C)(C)CCC2(C)C ; "M60"]

### 1) Synthesis of Int89

Int89 (35 g, yield 74%) was obtained using the same method and equivalents as in Synthesis of Int85 except that Int84 and 8-(tert-butyl)-N-(3,5,5,8,8-pentamethyl-5,6,7,8-tetrahydro-naphthalen-2-yl)dibenzo[b,d]furan-2-amine were used under a nitrogen atmosphere. MS[M+H]+=938

### 2) Synthesis of Int90

After introducing Int89 (25 g) and boron triiodide (17.8 g) to 1,2-dichlorobenzene (250 ml), the mixture was stirred for 4 hours at 160° C. After the reaction was finished, the result was extracted and then recrystallized to obtain Int90 (7.4 g, yield 29%). MS[M+H]+=1008

### 3) Synthesis of Compound M60

After introducing Int90 (7 g), 3-(tert-butyl)-N-(4-(tert-butyl)phenyl)aniline (2.1 g), sodium-tert-butoxide (2.1 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M60 (5.9 g, yield 67%). MS[M+H]+=1191

### Synthesis Example 61. Synthesis of Compound M61

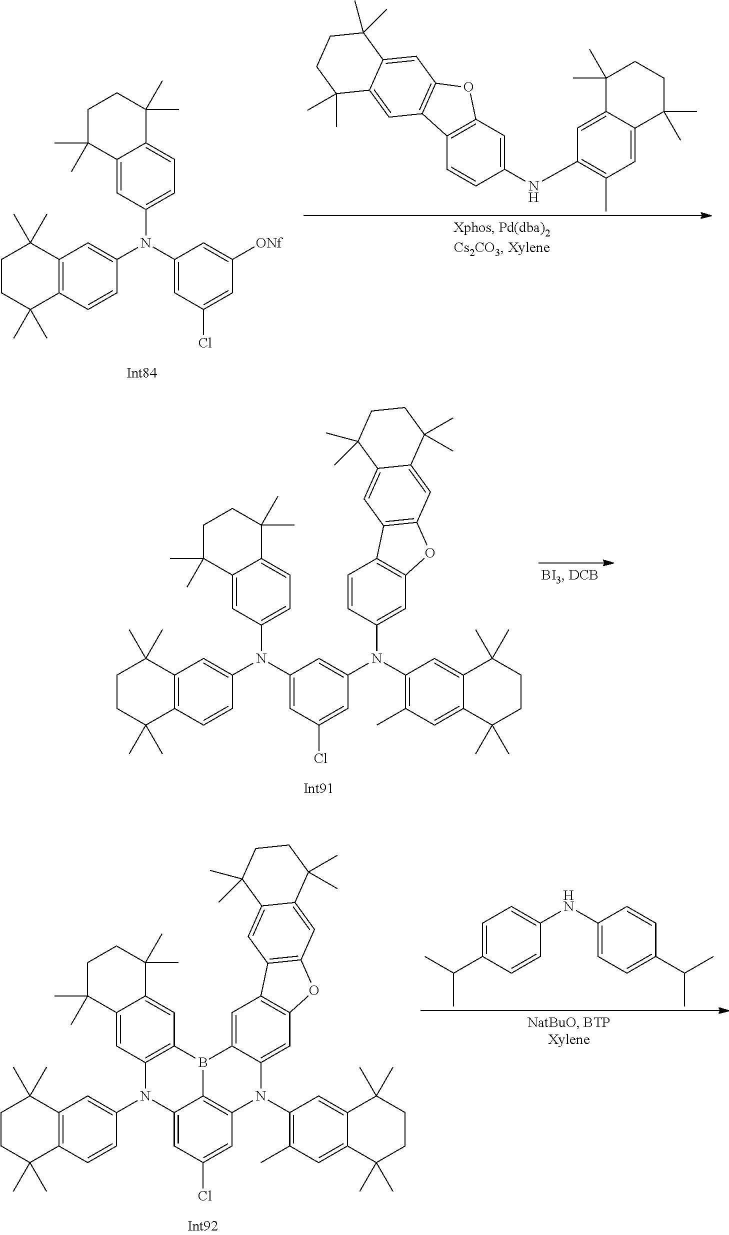

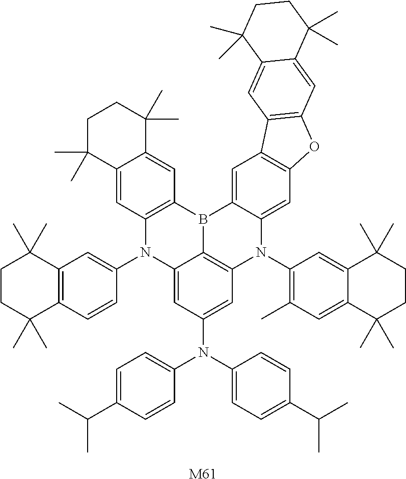 [SMILES: Cc1cc2c(cc1N1c3cc4oc5cc6c(cc5c4cc3B3c4cc5c(cc4N(c4ccc7c(c4)C(C)(C)CCC7(C)C)c4cc(N(c7ccc(C(C)C)cc7)c7ccc(C(C)C)cc7)cc1c43)C(C)(C)CCC5(C)C)C(C)(C)CCC6(C)C)C(C)(C)CCC2(C)C ; "M61"]

### 1) Synthesis of Int91

Int91 (36 g, yield 72%) was obtained using the same method and equivalents as in Synthesis of Int85 except that Int84 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-3-amine were used under a nitrogen atmosphere. MS[M+H]+=992

### 2) Synthesis of Int92

After introducing Int91 (25 g) and boron triiodide (16.8 g) to 1,2-dichlorobenzene (250 ml), the mixture was stirred for 4 hours at 160° C. After the reaction was finished, the result was extracted and then recrystallized to obtain Int92 (7.3 g, yield 29%). MS[M+H]+=1000

### 3) Synthesis of Compound M61

After introducing Int92 (7 g), bis(4-isopropylphenyl)amine (1.8 g), sodium-tert-butoxide (2.1 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M61 (6.1 g, yield 72%). MS[M+H]+=1217

### Synthesis Example 62. Synthesis of Compound M62

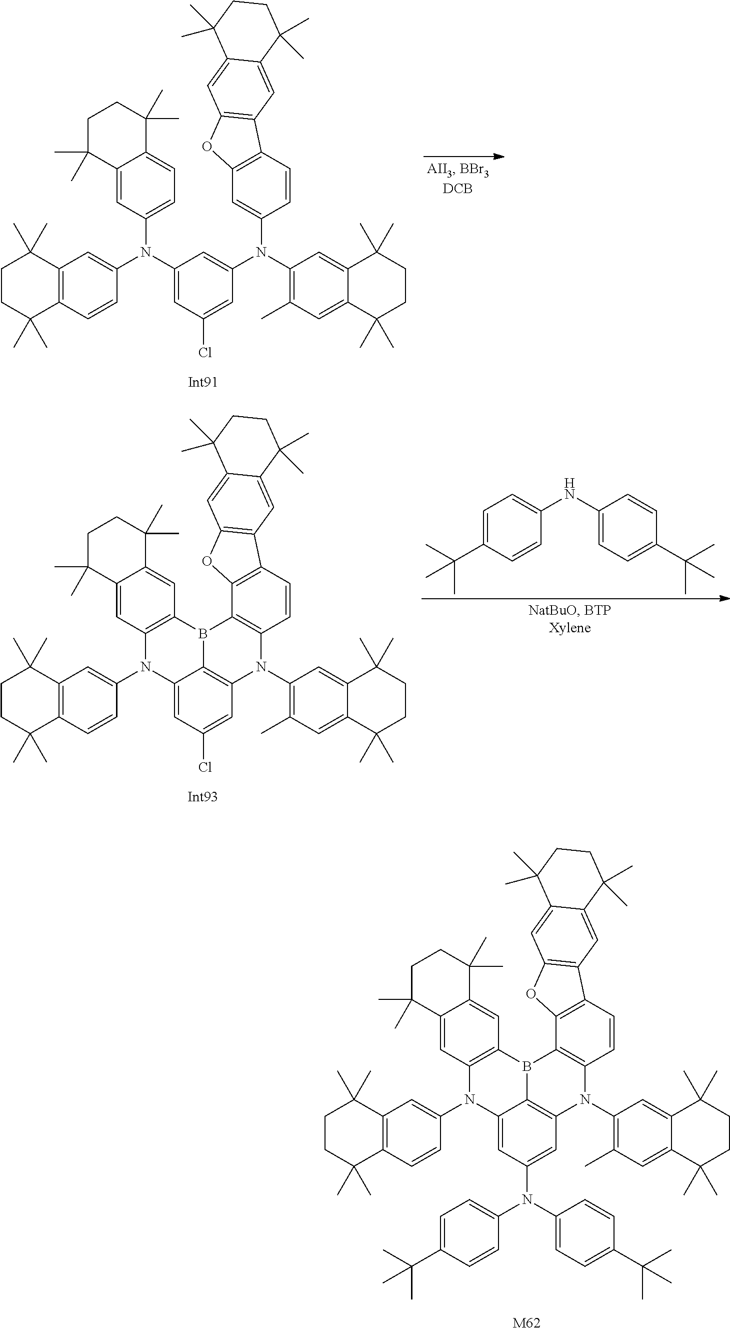

### 1) Synthesis of Int93

After introducing Int91 (25 g), aluminum iodide (4.1 g) and boron tribromide (19.1 ml) to 1,2-dichlorobenzene (250 ml), the mixture was stirred for 8 hours at 160° C. After the reaction was finished, the result was extracted, then passed through a column and then recrystallized to obtain Int93 (7.4 g, yield 29%). MS[M+H]+=1000

### 2) Synthesis of Compound M62

After introducing Int93 (7 g), bis(4-(tert-butyl)phenyl)amine (2.0 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M62 (6.2 g, yield 71%). MS[M+H]+=1245

### Synthesis Example 63. Synthesis of Compound M63

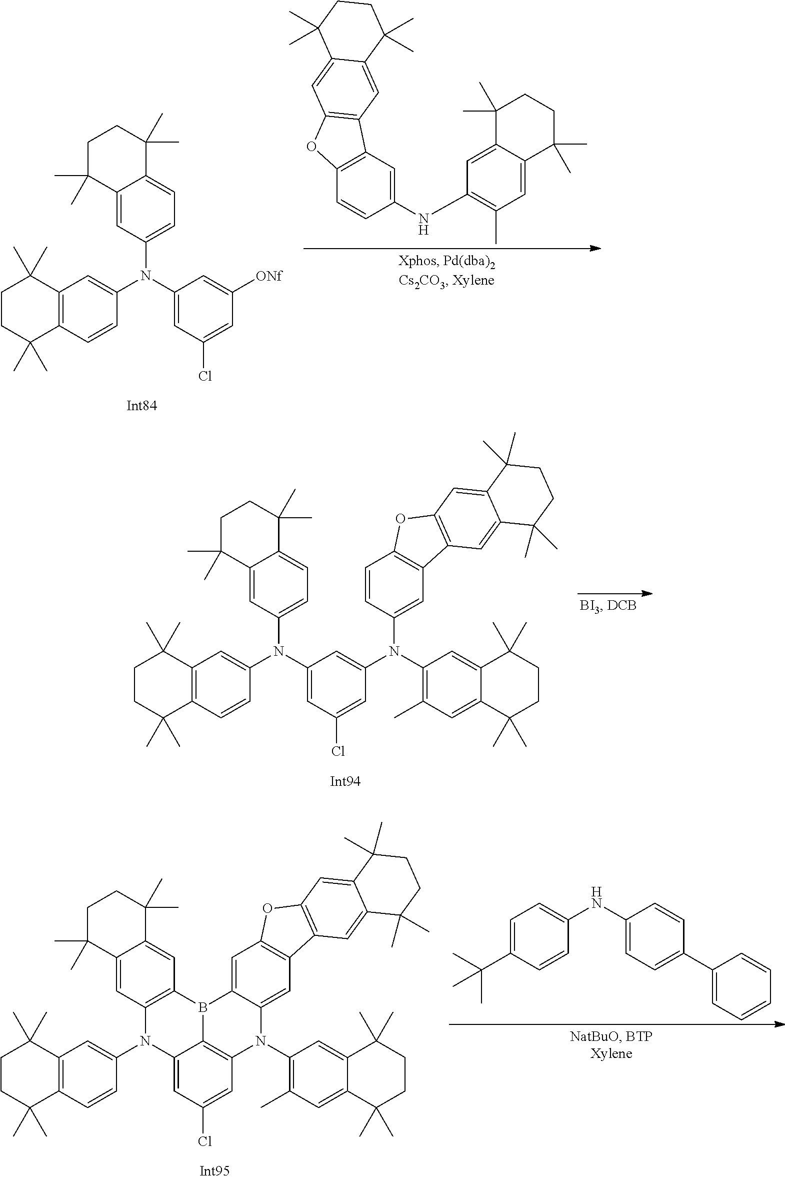

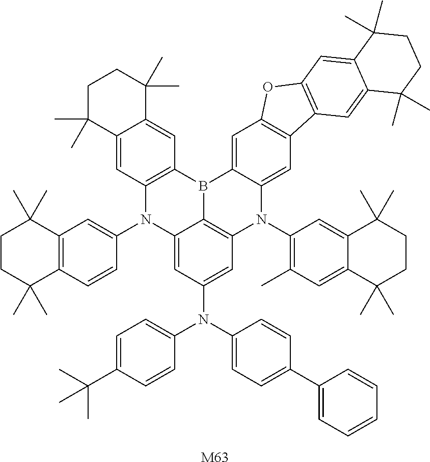 [SMILES: Cc1cc2c(cc1N1c3cc4c(cc3B3c5cc6c(cc5N(c5ccc7c(c5)C(C)(C)CCC7(C)C)c5cc(N(c7ccc(-c8ccccc8)cc7)c7ccc(C(C)(C)C)cc7)cc1c53)C(C)(C)CCC6(C)C)oc1cc3c(cc14)C(C)(C)CCC3(C)C)C(C)(C)CCC2(C)C ; "M63"]

### 1) Synthesis of Int94

Int94 (35 g, yield 70%) was obtained using the same method and equivalents as in Synthesis of Int85 except that Int84 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-2-amine were used under a nitrogen atmosphere. MS[M+H]+=992

### 2) Synthesis of Int95

After introducing Int94 (25 g) and boron triiodide (16.8 g) to 1,2-dichlorobenzene (250 ml), the mixture was stirred for 4 hours at 160° C. After the reaction was finished, the result was extracted and then recrystallized to obtain Int95 (7.1 g, yield 28%). MS[M+H]+=1000

### 3) Synthesis of Compound M63

After introducing Int95 (7 g), N-(4-(tert-butyl)phenyl)-[1,1′-biphenyl]-4-amine (2.2 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M63 (6.4 g, yield 72%). MS[M+H]+=1265

### Synthesis Example 64. Synthesis of Compound M64

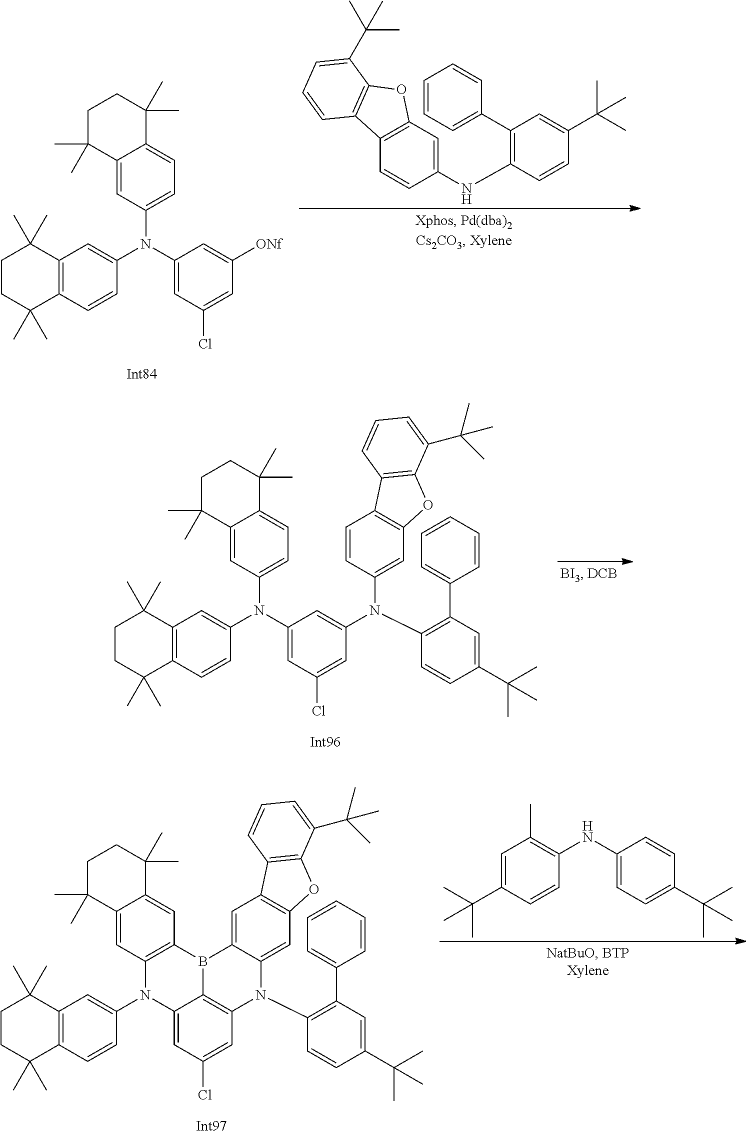

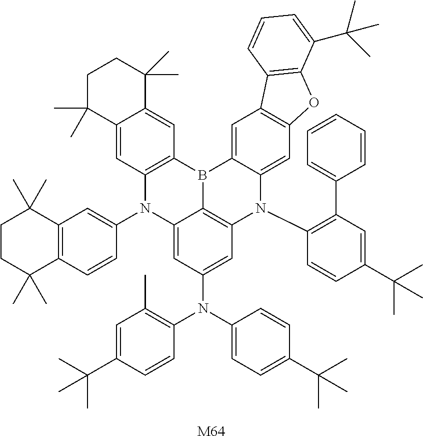 [SMILES: Cc1cc(C(C)(C)C)ccc1N(c1ccc(C(C)(C)C)cc1)c1cc2c3c(c1)N(c1ccc(C(C)(C)C)cc1-c1ccccc1)c1cc4oc5c(C(C)(C)C)cccc5c4cc1B3c1cc3c(cc1N2c1ccc2c(c1)C(C)(C)CCC2(C)C)C(C)(C)CCC3(C)C ; "M64"]

### 1) Synthesis of Int96

Int96 (33 g, yield 70%) was obtained using the same method and equivalents as in Synthesis of Int85 except that Int84 and 6-(tert-butyl)-N-(5-(tert-butyl)-[1,1′-biphenyl]-2-yl)dibenzo[b,d]furan-3-amine were used under a nitrogen atmosphere. MS[M+H]+=946

### 2) Synthesis of Int97

After introducing Int96 (25 g) and boron triiodide (17.6 g) to 1,2-dichlorobenzene (250 ml), the mixture was stirred for 4 hours at 160° C. After the reaction was finished, the result was extracted and then recrystallized to obtain Int97 (7.3 g, yield 29%). MS[M+H]+=954

### 3) Synthesis of Compound M64

After introducing Int97 (7 g), 4-(tert-butyl)-N-(4-(tert-butyl)phenyl)-2-methylaniline (2.2 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M64 (6.6 g, yield 74%). MS[M+H]+=1213

### Synthesis Example 65. Synthesis of Compound M65

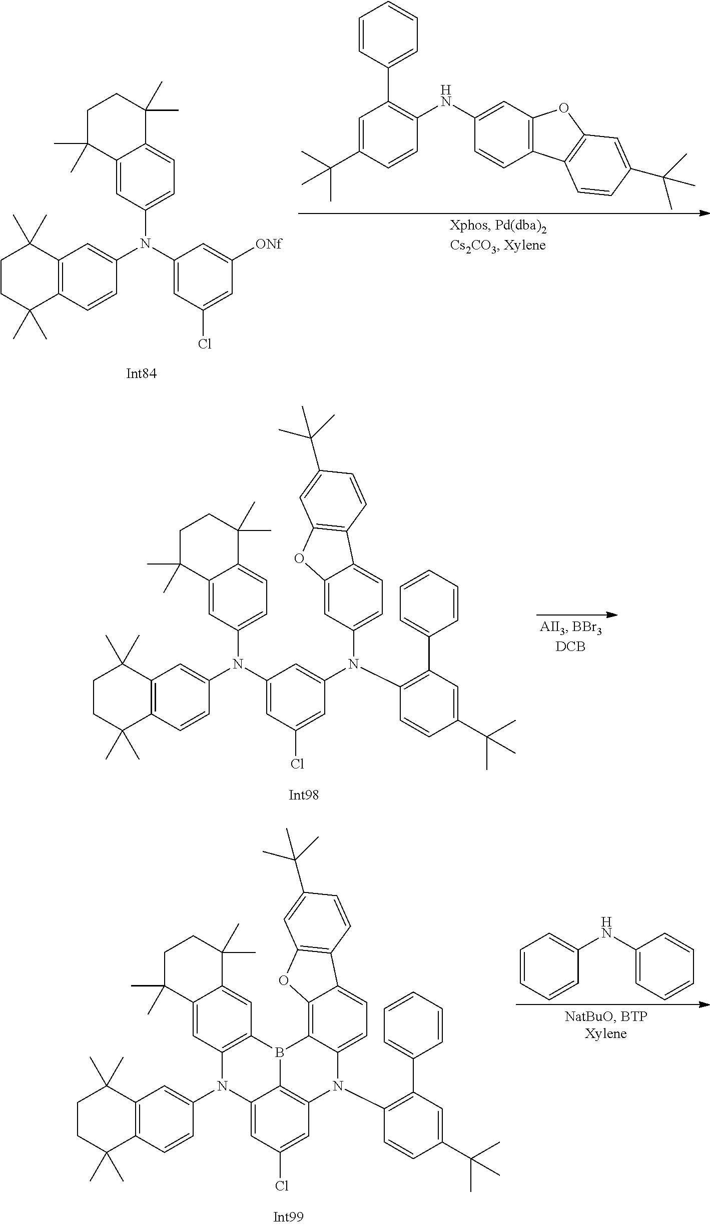

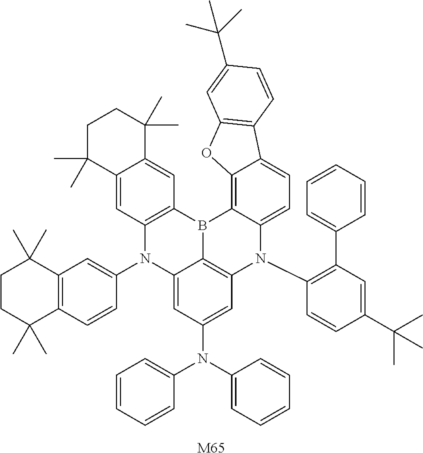 [SMILES: CC(C)(C)c1ccc(N2c3cc(N(c4ccccc4)c4ccccc4)cc4c3B(c3cc5c(cc3N4c3ccc4c(c3)C(C)(C)CCC4(C)C)C(C)(C)CCC5(C)C)c3c2ccc2c3oc3cc(C(C)(C)C)ccc32)c(-c2ccccc2)c1 ; "M65"]

### 1) Synthesis of Int98

Int98 (34 g, yield 72%) was obtained using the same method and equivalents as in Synthesis of Int85 except that Int84 and 7-(tert-butyl)-N-(5-(tert-butyl)-[1,1′-biphenyl]-2-yl)-dibenzo[b,d]furan-3-amine were used under a nitrogen atmosphere. MS[M+H]+=946

### 2) Synthesis of Int99

After introducing Int98 (25 g), aluminum iodide (4.3 g) and boron tribromide (20.1 ml) to 1,2-dichlorobenzene (250 ml), the mixture was stirred for 8 hours at 160° C. After the reaction was finished, the result was extracted, then passed through a column and then recrystallized to obtain Int99 (7.5 g, yield 30%). MS[M+H]+=954

### 3) Synthesis of Compound M65

After introducing Int99 (7 g), diphenylamine (1.3 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M65 (6.1 g, yield 76%). MS[M+H]+=1087

### Synthesis Example 66. Synthesis of Compound M66

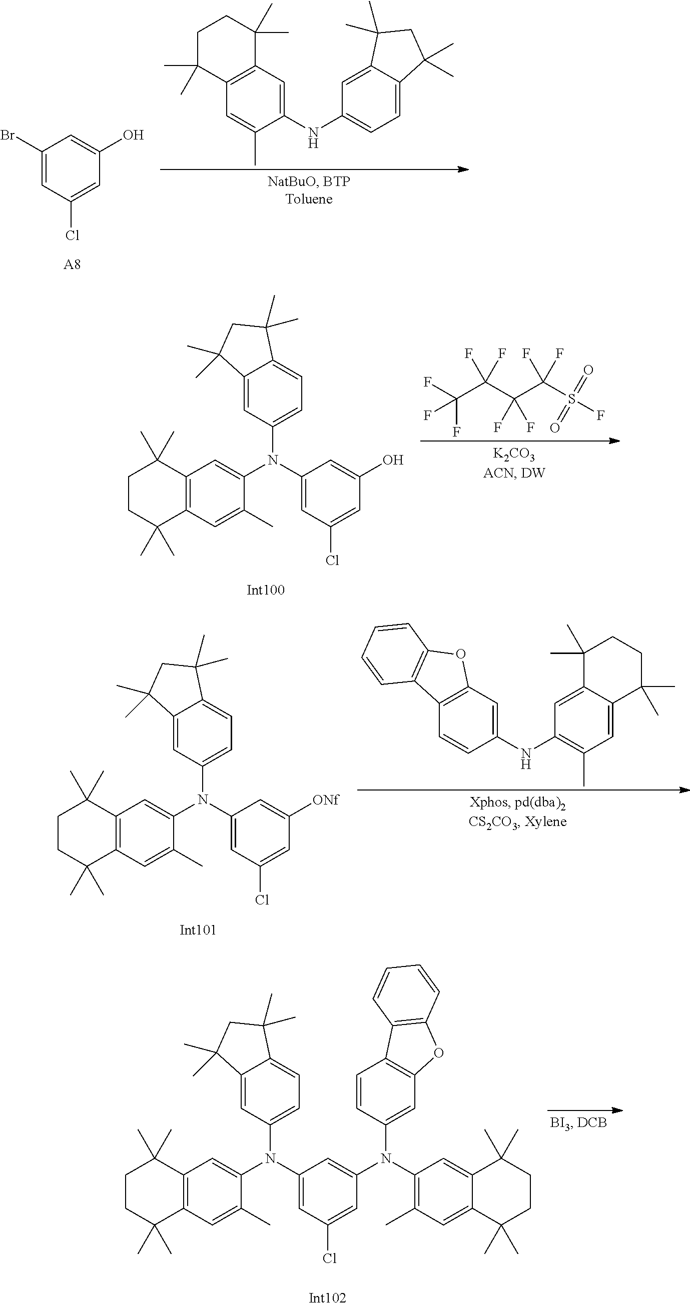

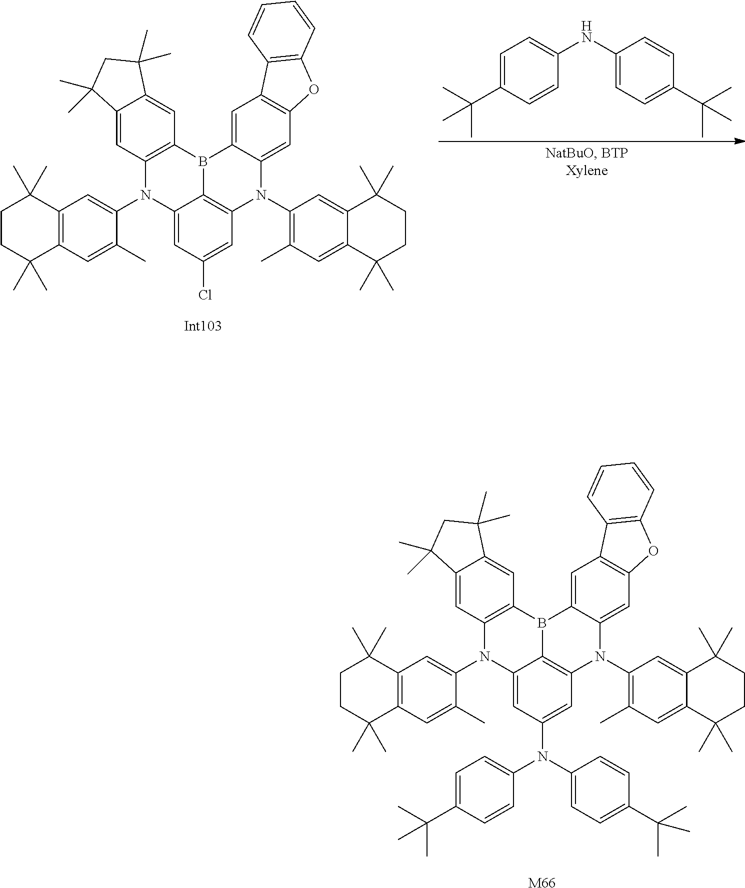 [SMILES: Cc1cc2c(cc1N1c3cc4c(cc3B3c5cc6c(cc5N(c5cc7c(cc5C)C(C)(C)CCC7(C)C)c5cc(Cl)cc1c53)oc1ccccc16)C(C)(C)CC4(C)C)C(C)(C)CCC2(C)C ; CC(C)(C)c1ccc(Nc2ccc(C(C)(C)C)cc2)cc1 ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)oc1ccccc16)C(C)(C)CC4(C)C)C(C)(C)CCC2(C)C ; "M66"]

### 1) Synthesis of Int100

Int100 (55 g, yield 74%) was obtained using the same method and equivalents as in Synthesis of Int83 except that A8 and 3,5,5,8,8-pentamethyl-N-(1,1,3,3-tetramethyl-2,3-dihydro-1H-inden-5-yl)-5,6,7,8-tetrahydronaphthalen-2-amine were used under a nitrogen atmosphere. MS[M+H]+=517

### 2) Synthesis of Int101

Int101 (56 g, yield 91%) was obtained using the same method and equivalents as in Synthesis of Int84 except that Int100 was used under a nitrogen atmosphere. MS[M+H]+=799

### 3) Synthesis of Int102

Int102 (33 g, yield 75%) was obtained using the same method and equivalents as in Synthesis of Int85 except that

Int101 and N-(3,5,5,8,8-pentamethyl-5,6,7,8-tetrahydronaphthalen-2-yl)dibenzo[b,d]furan-3-amine were used under a nitrogen atmosphere. MS[M+H]+=882

### 4) Synthesis of Int103

After introducing Int102 (25 g) and boron triiodide (18.9 g) to 1,2-dichlorobenzene (250 ml), the mixture was stirred for 4 hours at 160° C. After the reaction was finished, the result was extracted and then recrystallized to obtain Int103 (7.4 g, yield 29%). MS[M+H]+=890

### 5) Synthesis of Compound M66

After introducing Int103 (7 g), bis(4-(tert-butyl)phenyl)amine (1.4 g), sodium-tert-butoxide (1.5 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M66 (6.4 g, yield 72%). MS[M+H]+=1135

### Synthesis Example 67. Synthesis of Compound M67

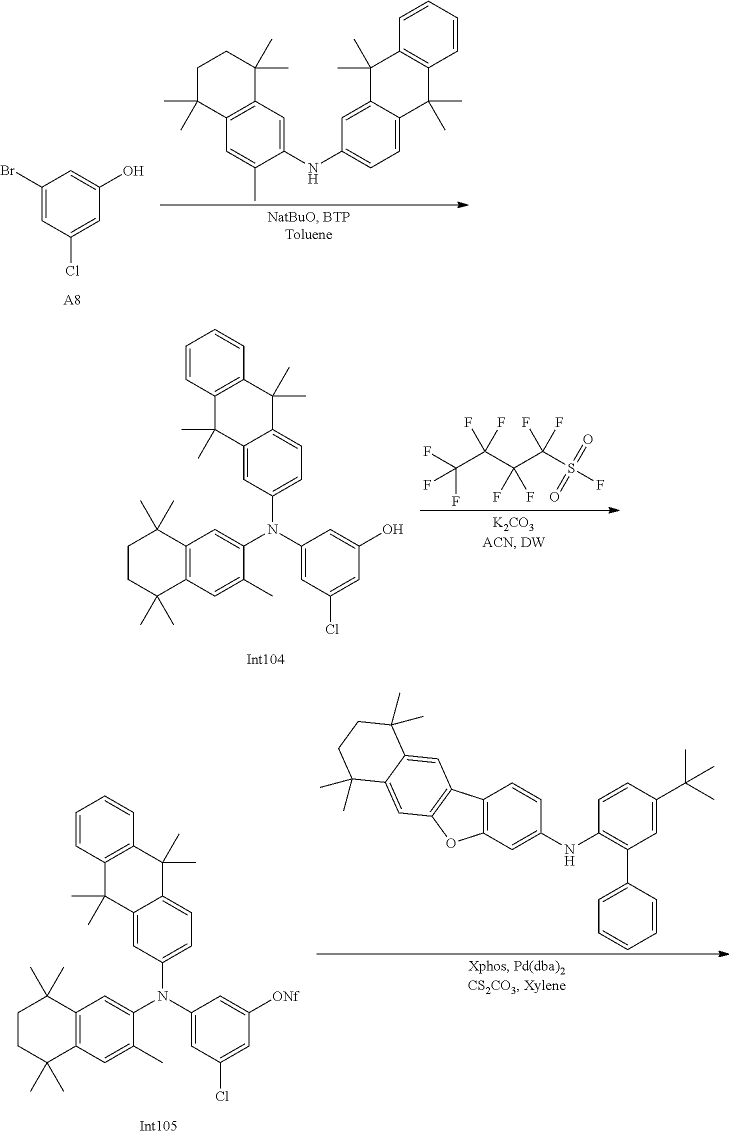

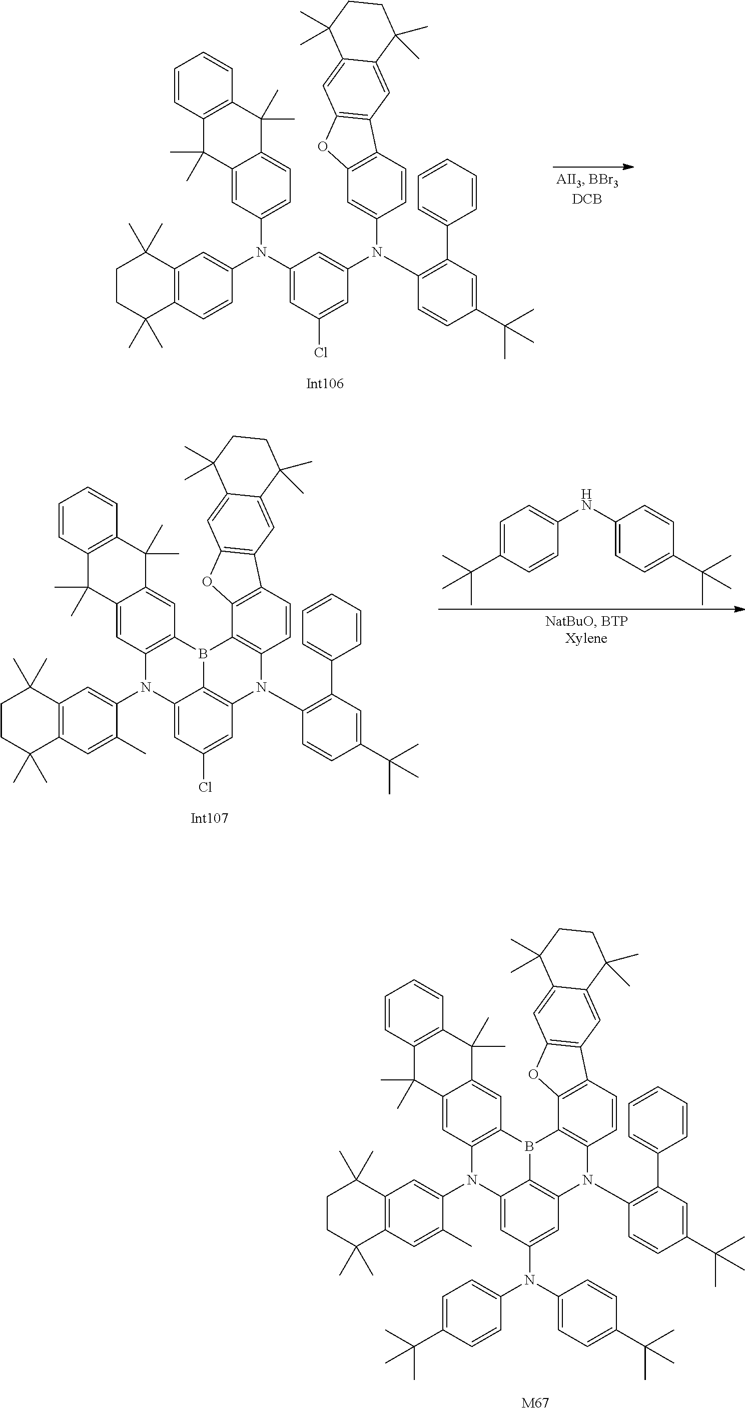

### 1) Synthesis of Int104

Int104 (59 g, yield 71%) was obtained using the same method and equivalents as in Synthesis of Int83 except that A8 and 9,9,10,10-tetramethyl-N-(3,5,5,8,8-pentamethyl-5,6,7,8-tetrahydronaphthalen-2-yl)-9,10-dihydroanthracen-2-amine were used under a nitrogen atmosphere. MS[M+H]+=579

### 2) Synthesis of Int105

Int105 (55 g, yield 92%) was obtained using the same method and equivalents as in Synthesis of Int84 except that Int104 was used under a nitrogen atmosphere. MS[M+H]+=861

### 3) Synthesis of Int106

Int106 (35 g, yield 71%) was obtained using the same method and equivalents as in Synthesis of Int85 except that Int105 and N-(5-(tert-butyl)-[1,1′-biphenyl]-2-yl)-7,7,10,10-tetramethyl-7,8,9,10-tetrahydronaphtho[2,3-b]benzofuran-3-amine were used under a nitrogen atmosphere. MS[M+H]+=1062

### 4) Synthesis of Int107

After introducing Int106 (25 g), aluminum iodide (3.9 g) and boron tribromide (17.8 ml) to 1,2-dichlorobenzene (250 ml), the mixture was stirred for 8 hours at 160° C. After the reaction was finished, the result was extracted, then passed through a column and then recrystallized to obtain Int107 (7.1 g, yield 28%). MS[M+H]+=1070

### 5) Synthesis of Compound M67

After introducing Int107 (7 g), bis(4-(tert-butyl)phenyl)amine (1.1 g), sodium-tert-butoxide (1.3 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M67 (6.5 g, yield 76%). MS[M+H]+=1315

### Synthesis Example 68. Synthesis of Compound M68

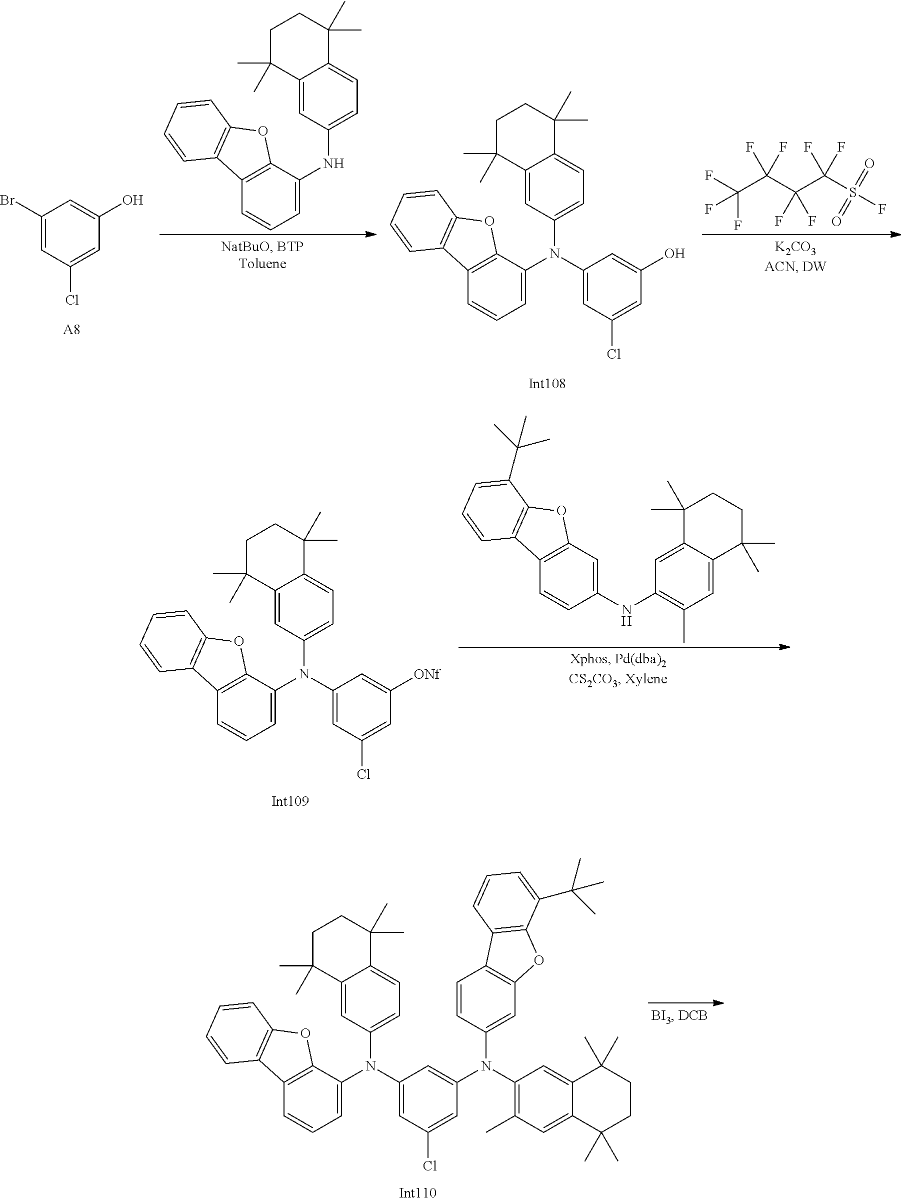

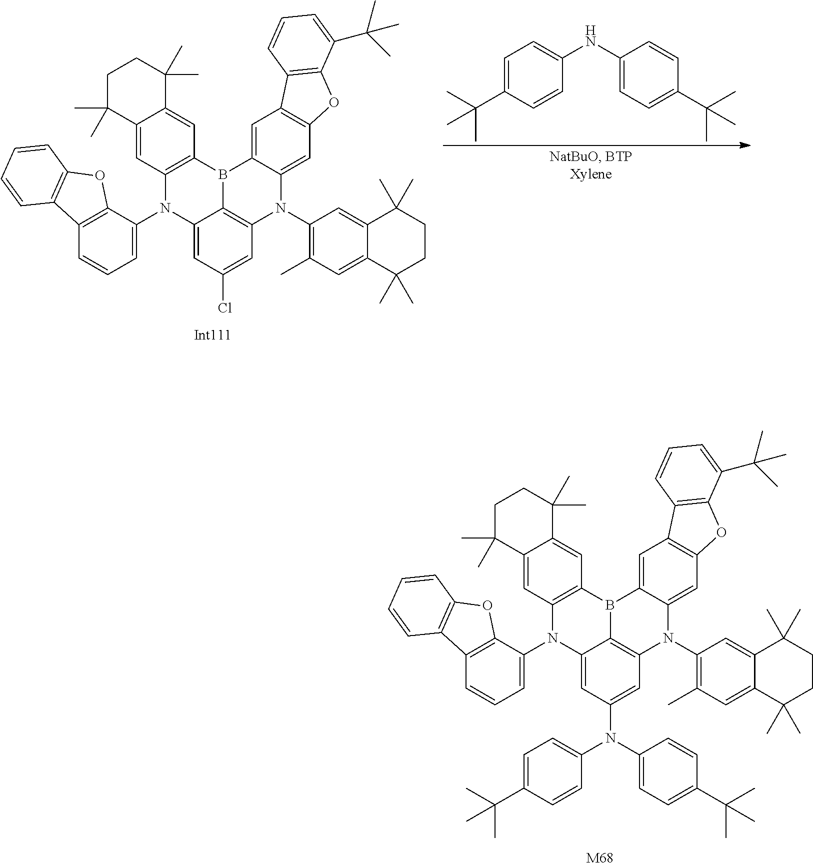 [SMILES: Cc1cc2c(cc1N1c3cc4oc5c(C(C)(C)C)cccc5c4cc3B3c4cc5c(cc4N(c4cccc6c4oc4ccccc46)c4cc(Cl)cc1c43)C(C)(C)CCC5(C)C)C(C)(C)CCC2(C)C ; CC(C)(C)c1ccc(Nc2ccc(C(C)(C)C)cc2)cc1 ; Cc1cc2c(cc1N1c3cc4oc5c(C(C)(C)C)cccc5c4cc3B3c4cc5c(cc4N(c4cccc6c4oc4ccccc46)c4cc(N(c6ccc(C(C)(C)C)cc6)c6ccc(C(C)(C)C)cc6)cc1c43)C(C)(C)CCC5(C)C)C(C)(C)CCC2(C)C ; "M68"]

### 1) Synthesis of Int108

Int108 (54 g, yield 75%) was obtained using the same method and equivalents as in Synthesis of Int83 except that A8 and N-(5,5,8,8-tetramethyl-5,6,7,8-tetrahydronaphthalen-2-yl)dibenzo[b,d]furan-4-amine were used under a nitrogen atmosphere. MS[M+H]+=497

### 2) Synthesis of Int109

Int109 (58 g, yield 92%) was obtained using the same method and equivalents as in Synthesis of Int84 except that Int108 was used under a nitrogen atmosphere. MS[M+H]+=779

### 3) Synthesis of Int110

Int110 (37 g, yield 78%) was obtained using the same method and equivalents as in Synthesis of Int85 except that Int109 and 6-(tert-butyl)-N-(3,5,5,8,8-pentamethyl-5,6,7,8-tetrahydronaphthalen-2-yl)dibenzo[b,d]furan-3-amine were used under a nitrogen atmosphere. MS[M+H]+=918

### 4) Synthesis of Int111

After introducing Int110 (25 g) and boron triiodide (18.2 g) to 1,2-dichlorobenzene (250 ml), the mixture was stirred for 4 hours at 160° C. After the reaction was finished, the result was extracted and then recrystallized to obtain Int111 (7.4 g, yield 29%). MS[M+H]+=926

### 5) Synthesis of Compound M68

After introducing Int111 (7 g), bis(4-(tert-butyl)phenyl)amine (2.1 g), sodium-tert-butoxide (1.5 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M68 (6.6 g, yield 75%). MS[M+H]+=1171

### Synthesis Example 69. Synthesis of Compound M69

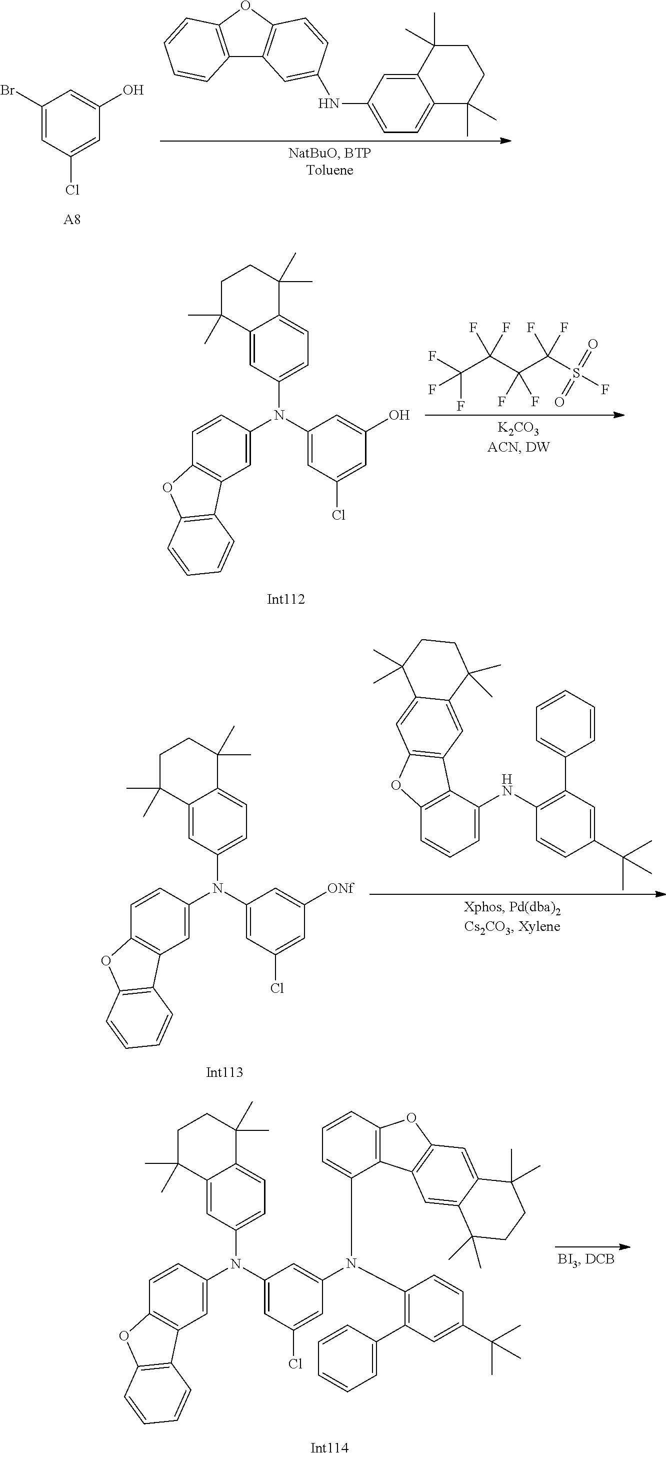

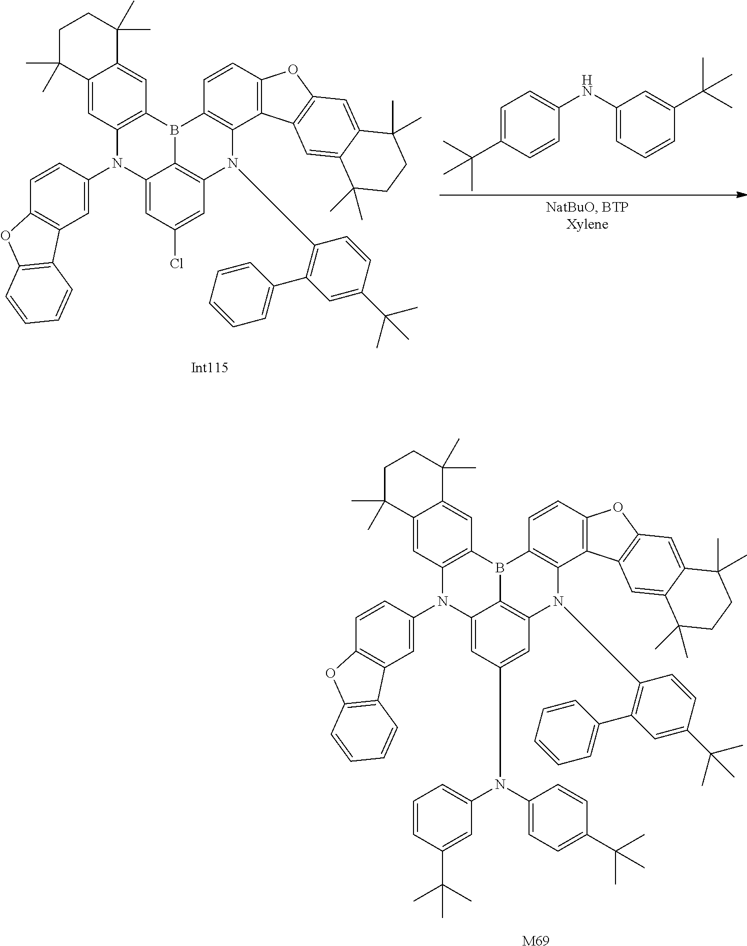

### 1) Synthesis of Int112

Int112 (53 g, yield 74%) was obtained using the same method and equivalents as in Synthesis of Int83 except that A8 and N-(5,5,8,8-tetramethyl-5,6,7,8-tetrahydronaphthalen-2-yl)dibenzo[b,d]furan-2-amine were used under a nitrogen atmosphere. MS[M+H]+=497

### 2) Synthesis of Int113

Int113 (57 g, yield 92%) was obtained using the same method and equivalents as in Synthesis of Int84 except that Int112 was used under a nitrogen atmosphere. MS[M+H]+=779

### 3) Synthesis of Int114

Int114 (37 g, yield 73%) was obtained using the same method and equivalents as in Synthesis of Int85 except that Int113 and N-(5-(tert-butyl)-[1,1′-biphenyl]-2-yl)-7,7,10,10-tetramethyl-7,8,9,10-tetrahydronaphtho[2,3-b]benzofuran-1-amine were used under a nitrogen atmosphere. MS[M+H]+=980

### 4) Synthesis of Int115

After introducing Int114 (25 g) and boron triiodide (16.9 g) to 1,2-dichlorobenzene (250 ml), the mixture was stirred for 4 hours at 160° C. After the reaction was finished, the result was extracted and then recrystallized to obtain Int115 (7.2 g, yield 29%). MS[M+H]+=988

### 5) Synthesis of Compound M69

After introducing Int115 (7 g), 3-(tert-butyl)-N-(4-(tert-butyl)phenyl) aniline (2.0 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M69 (6.4 g, yield 73%). MS[M+H]+=1233

### Synthesis Example 70. Synthesis of Compound M70

### 1) Synthesis of Int116

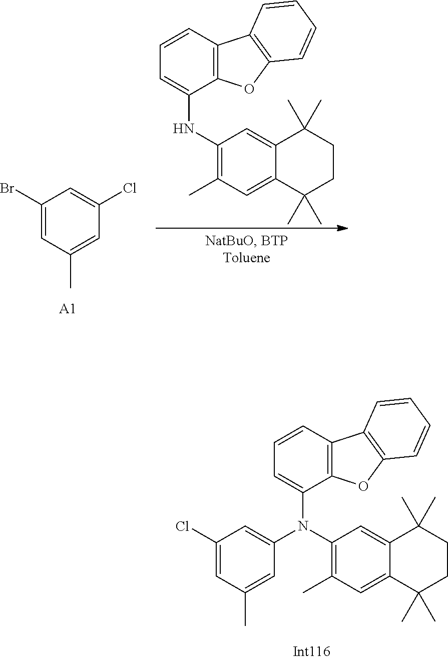

After introducing A1 (30 g), N-(3,5,5,8,8-pentamethyl-5,6,7,8-tetrahydronaphthalen-2-yl)dibenzo[b,d]furan-4-amine (56.9 g), sodium-tert-butoxide (42.1 g) and bis(tri-tert-butylphosphine)palladium(0) (1.5 g) to toluene (600 ml), the mixture was refluxed for 1 hour. After the reaction was finished, the result was extracted, and then recrystallized to obtain Int116 (55 g, yield 74%). MS[M+H]+=509

### 2) Synthesis of Int117

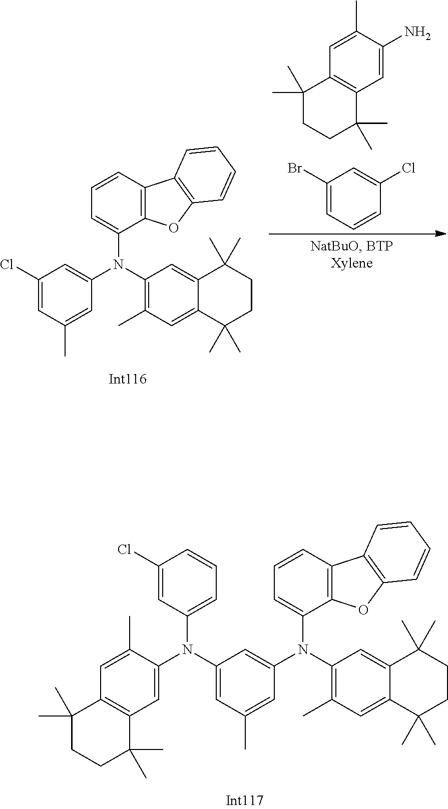

After introducing Int116 (30 g), 3,5,5,8,8-pentamethyl-5,6,7,8-tetrahydronaphthalen-2-amine (12.8 g), sodium-tert-butoxide (11.4 g) and bis(tri-tert-butylphosphine)palladium(0) (0.3 g) to xylene (600 ml), the mixture was refluxed for 1 hour, and after checking the progress of the reaction, 1-bromo-3-chlorobenzene (11.3 g) was introduced thereto. After the reaction was finished, the result was extracted and then recrystallized to obtain Int117 (35 g, yield 74%). MS[M+H]+=800

### 3) Synthesis of Int118

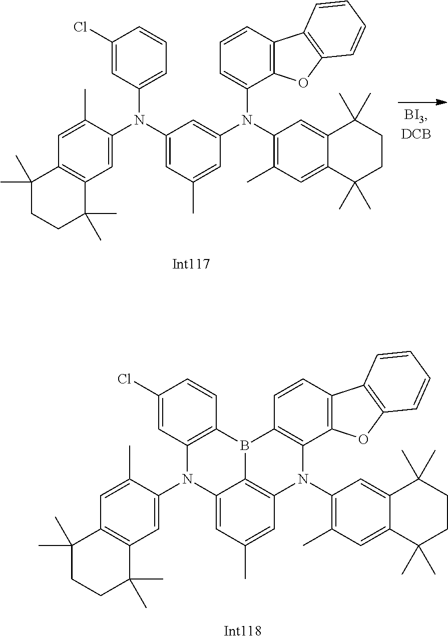 [SMILES: Cc1cc(N(c2cccc(Cl)c2)c2cc3c(cc2C)C(C)(C)CCC3(C)C)cc(N(c2cc3c(cc2C)C(C)(C)CCC3(C)C)c2cccc3c2oc2ccccc23)c1 ; Cc1cc2c3c(c1)N(c1cc4c(cc1C)C(C)(C)CCC4(C)C)c1c(ccc4c1oc1ccccc14)B3c1ccc(Cl)cc1N2c1cc2c(cc1C)C(C)(C)CCC2(C)C]

After introducing Int117 (25 g) and boron triiodide (20.8 g) to 1,2-dichlorobenzene (250 ml) under a nitrogen atmosphere, the mixture was stirred for 8 hours at 160° C. After the reaction was finished, the result was extracted and then recrystallized to obtain Int118 (7.4 g, yield 29%). MS[M+H]+=808

### 4) Synthesis of Compound M70

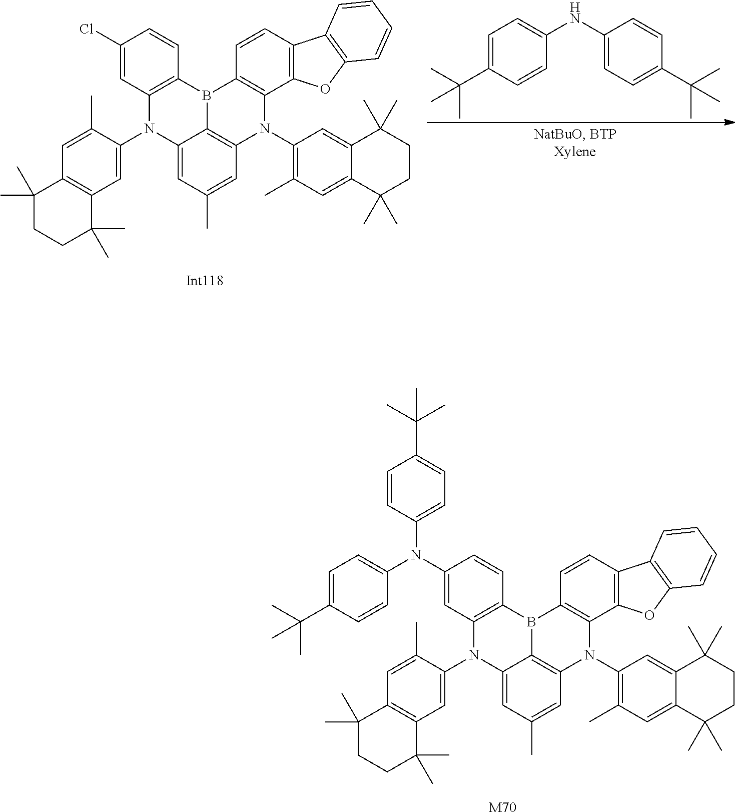

After introducing Int118 (7 g), bis(4-(tert-butyl)phenyl)amine (2.5 g), sodium-tert-butoxide (1.6 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M70 (6.5 g, yield 71%). MS[M+H]+=1053

### Synthesis Example 71. Synthesis of Compound M71

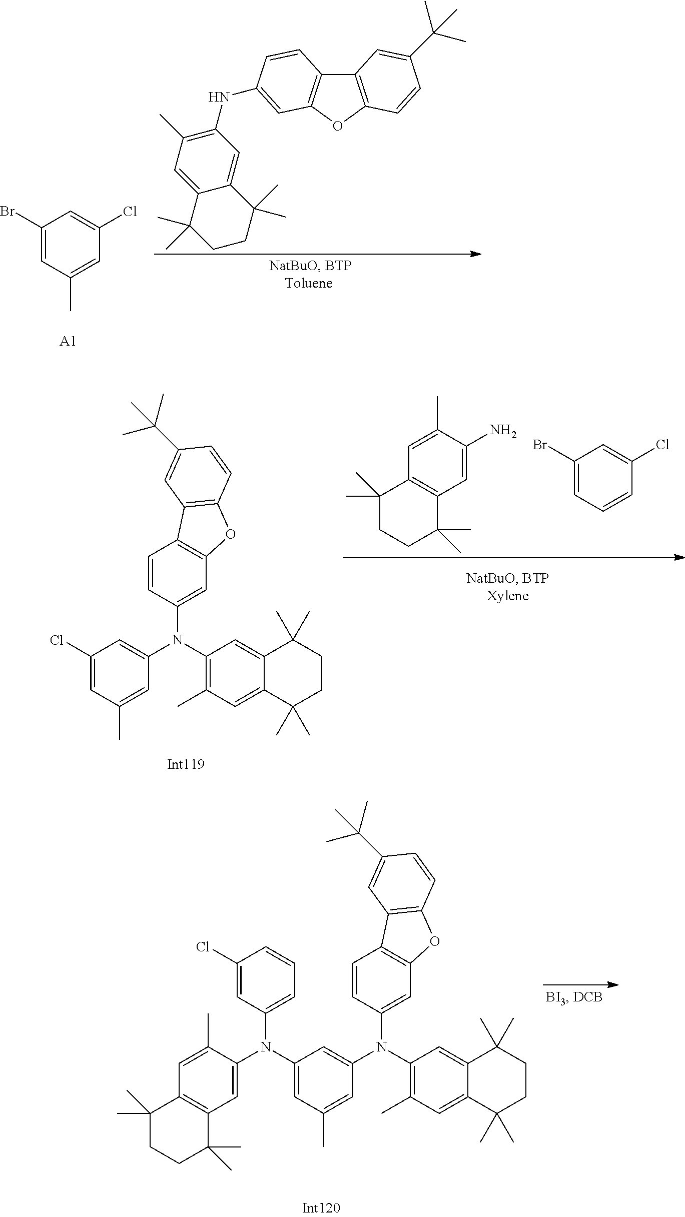

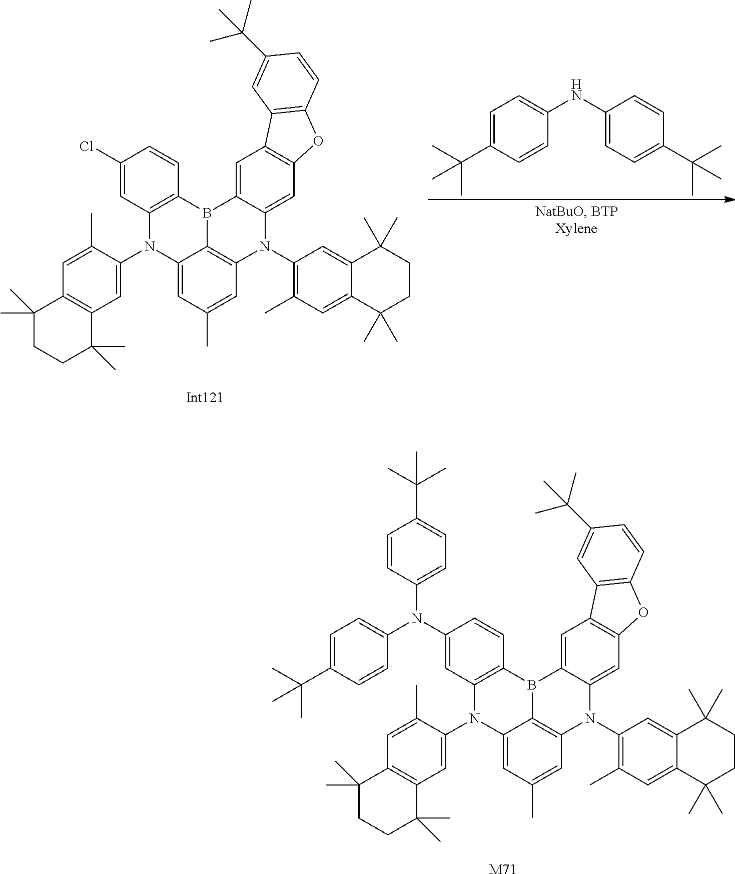 [SMILES: Cc1cc2c3c(c1)N(c1cc4c(cc1C)C(C)(C)CCC4(C)C)c1cc4oc5ccc(C(C)(C)C)cc5c4cc1B3c1ccc(Cl)cc1N2c1cc2c(cc1C)C(C)(C)CCC2(C)C ; CC(C)(C)c1ccc(Nc2ccc(C(C)(C)C)cc2)cc1 ; Cc1cc2c3c(c1)N(c1cc4c(cc1C)C(C)(C)CCC4(C)C)c1cc4oc5ccc(C(C)(C)C)cc5c4cc1B3c1ccc(N(c3ccc(C(C)(C)C)cc3)c3ccc(C(C)(C)C)cc3)cc1N2c1cc2c(cc1C)C(C)(C)CCC2(C)C ; "M71"]

### 1) Synthesis of Int119

Int119 (61 g, yield 74%) was obtained using the same method and equivalents as in Synthesis of Int116 except that A1 and 8-(tert-butyl)-N-(3,5,5,8,8-pentamethyl-5,6,7,8-tetrahydronaphthalen-2-yl)dibenzo[b,d]furan-3-amine were used under a nitrogen atmosphere. MS[M+H]+=565

### 2) Synthesis of Int120

Int120 (34 g, yield 75%) was obtained using the same method and equivalents as in Synthesis of Int117 except that Int119 was used under a nitrogen atmosphere. MS[M+H]+=856

### 3) Synthesis of Int121

After introducing Int120 (25 g) and boron triiodide (19.5 g) to 1,2-dichlorobenzene (250 ml), the mixture was stirred for 8 hours at 160° C. After the reaction was finished, the result was extracted and then recrystallized to obtain Int121 (7.5 g, yield 30%). MS[M+H]+=864

### 4) Synthesis of Compound M71

After introducing Int121 (7 g), bis(4-(tert-butyl)phenyl)amine (2.3 g), sodium-tert-butoxide (1.6 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M71 (6.6 g, yield 73%). MS[M+H]+=1109

### Synthesis Example 72. Synthesis of Compound M72

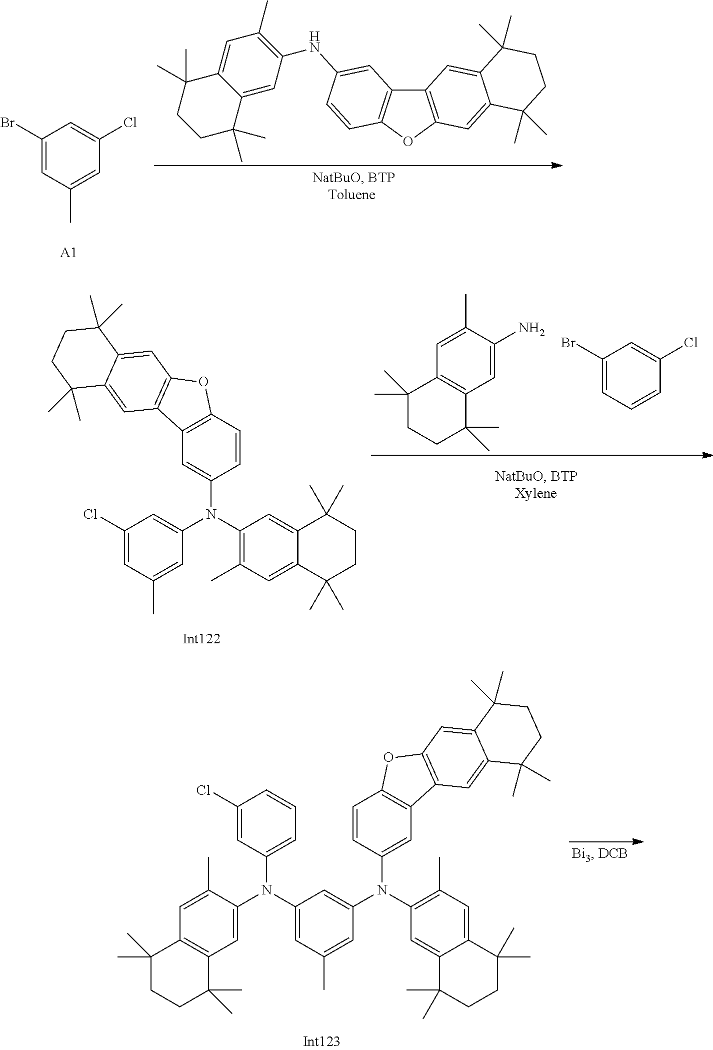

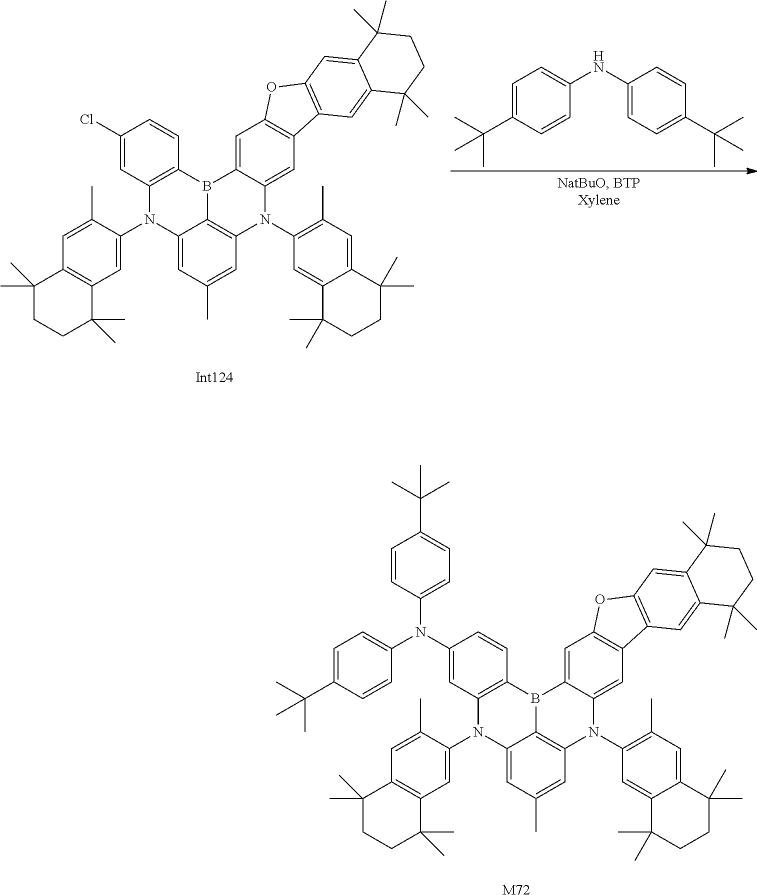

### 1) Synthesis of Int122

Int122 (62 g, yield 69%) was obtained using the same method and equivalents as in Synthesis of Int116 except that A1 and 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-2-amine were used under a nitrogen atmosphere. MS[M+H]+=619

### 2) Synthesis of Int123

Int123 (34 g, yield 77%) was obtained using the same method and equivalents as in Synthesis of Int117 except that Int122 was used under a nitrogen atmosphere. MS[M+H]+=910

### 3) Synthesis of Int124

After introducing Int123 (25 g) and boron triiodide (18.3 g) to 1,2-dichlorobenzene (250 ml), the mixture was stirred for 8 hours at 160° C. After the reaction was finished, the result was extracted and then recrystallized to obtain Int124 (7.5 g, yield 30%). MS[M+H]+=918

### 4) Synthesis of Compound M72

After introducing Int124 (7 g), bis(4-(tert-butyl)phenyl)amine (2.2 g), sodium-tert-butoxide (1.5 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M72 (6.5 g, yield 73%). MS[M+H]+=1163

### Synthesis Example 73. Synthesis of Compound M73

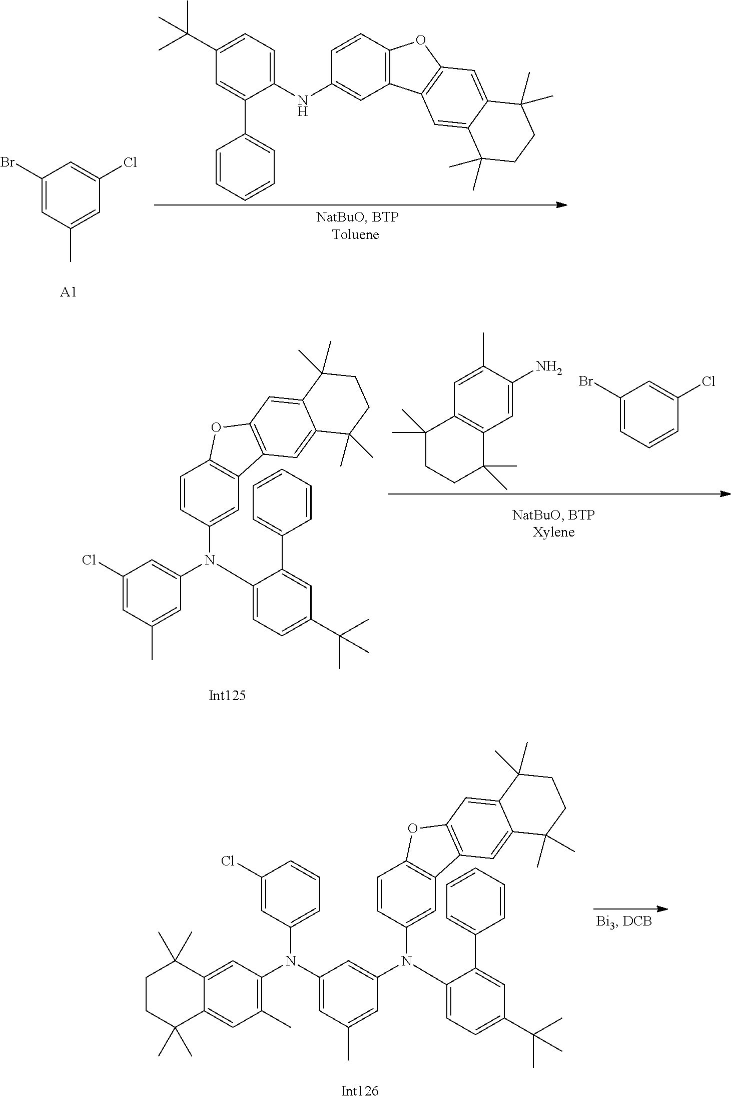

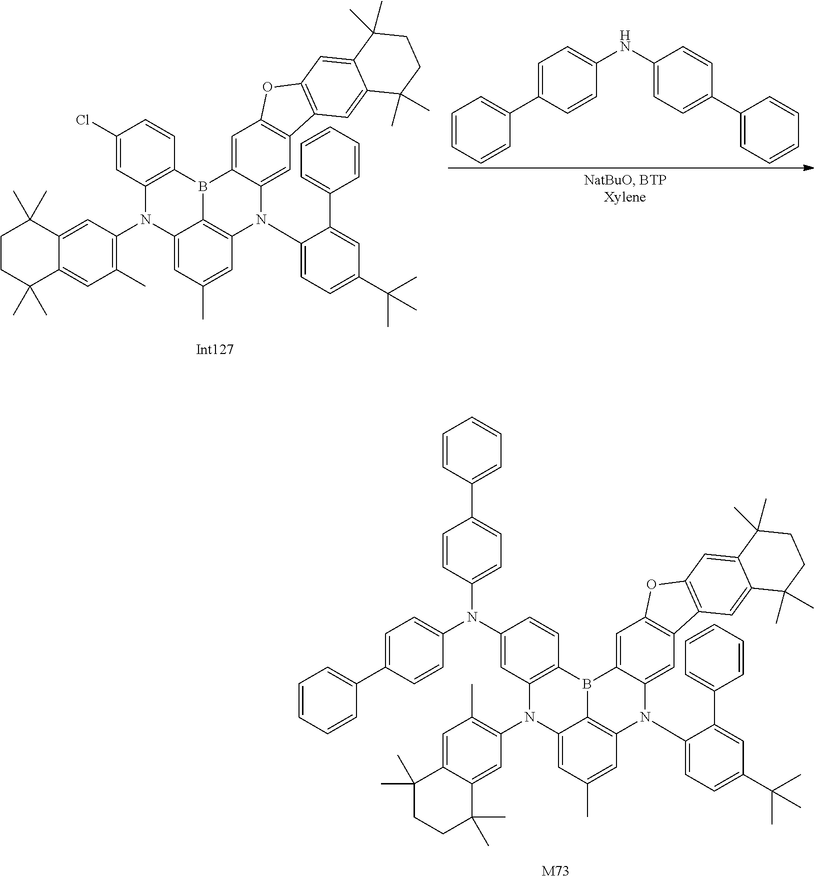

### 1) Synthesis of Int125

Int125 (63 g, yield 69%) was obtained using the same method and equivalents as in Synthesis of Int116 except that A1 and N-(5-(tert-butyl)-[1,1′-biphenyl]-2-yl)-7,7,10,10-tetramethyl-7,8,9,10-tetrahydronaphtho[2,3-b]benzofuran-2-amine were used under a nitrogen atmosphere. MS[M+H]+=627

### 2) Synthesis of Int126

Int126 (33 g, yield 75%) was obtained using the same method and equivalents as in Synthesis of Int117 except that Int125 was used under a nitrogen atmosphere. MS[M+H]+=918

### 3) Synthesis of Int127

After introducing Int126 (25 g) and boron triiodide (18.2 g) to 1,2-dichlorobenzene (250 ml), the mixture was stirred for 8 hours at 160° C. After the reaction was finished, the result was extracted and then recrystallized to obtain Int127 (7.4 g, yield 29%). MS[M+H]+=926

### 4) Synthesis of Compound M73

After introducing Int127 (7 g), di([1,1′-biphenyl]-4-yl)amine (2.4 g), sodium-tert-butoxide (1.5 g) and bis(tri-tert-butylphosphine)palladium(0) (0.04 g) to toluene (100 ml), under a nitrogen atmosphere the mixture was stirred for 6 hours under reflux. After the reaction was finished, the result was extracted and then recrystallized to obtain Compound M73 (6.6 g, yield 72%). MS[M+H]+=1211

### Synthesis Example 74. Synthesis of Compound M74

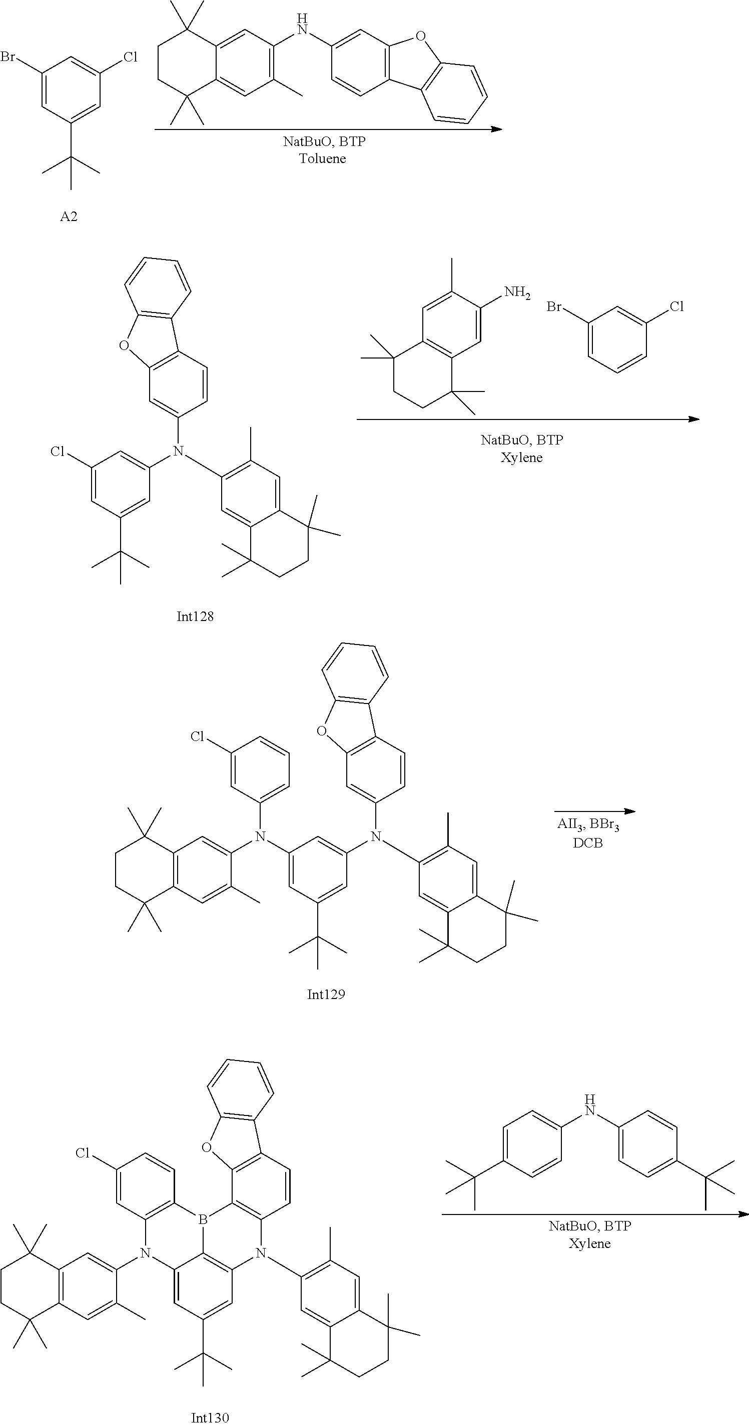

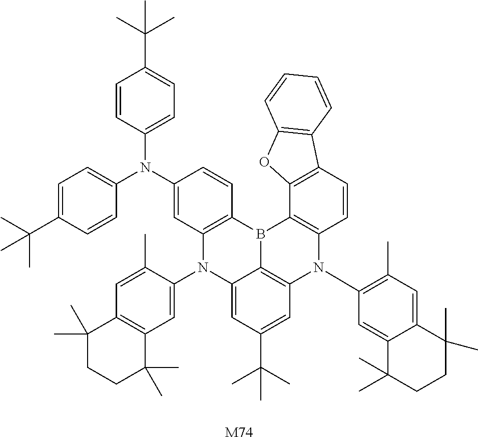

### 1) Synthesis of Int128

Int128 (47 g, yield 70%) was obtained using the same method and equivalents as in Synthesis of Int116 except that A2 and N-(3,5,5,8,8-pentamethyl-5,6,7,8-tetrahydronaphthalen-2-yl)dibenzo[b,d]furan-3-amine were used under a nitrogen atmosphere. MS[M+H]+=551

### 2) Synthesis of Int129

Int129 (32 g, yield 70%) was obtained using the same method and equivalents as in Synthesis of Int117 except that Int128 was used under a nitrogen atmosphere. MS[M+H]+=842

### 3) Synthesis of Int130

After introducing Int129 (25 g), aluminum iodide (4.9 g) and boron tribromide (22.5 ml) to 1,2-dichlorobenzene (250 ml), the mixture was stirred for 8 hours at 160° C. After the reaction was finished, the result was extracted, then passed through a column and then recrystallized to obtain Int130 (7.2 g, yield 29%). MS[M+H]+=850

### 4) Synthesis of Compound M74

After introducing Int130 (7 g), bis(4-(tert-butyl)phenyl)amine (2.3 g), sodium-tert-butoxide (1.6 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M74 (6.7 g, yield 74%). MS[M+H]+=1095

### Synthesis Example 75. Synthesis of Compound M75

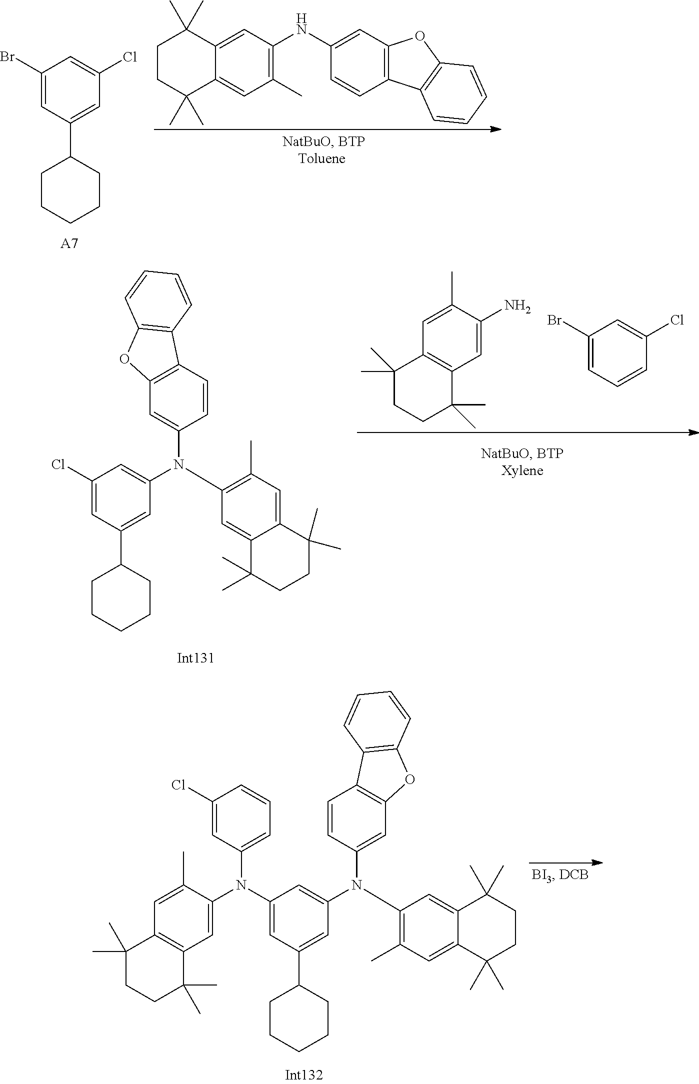

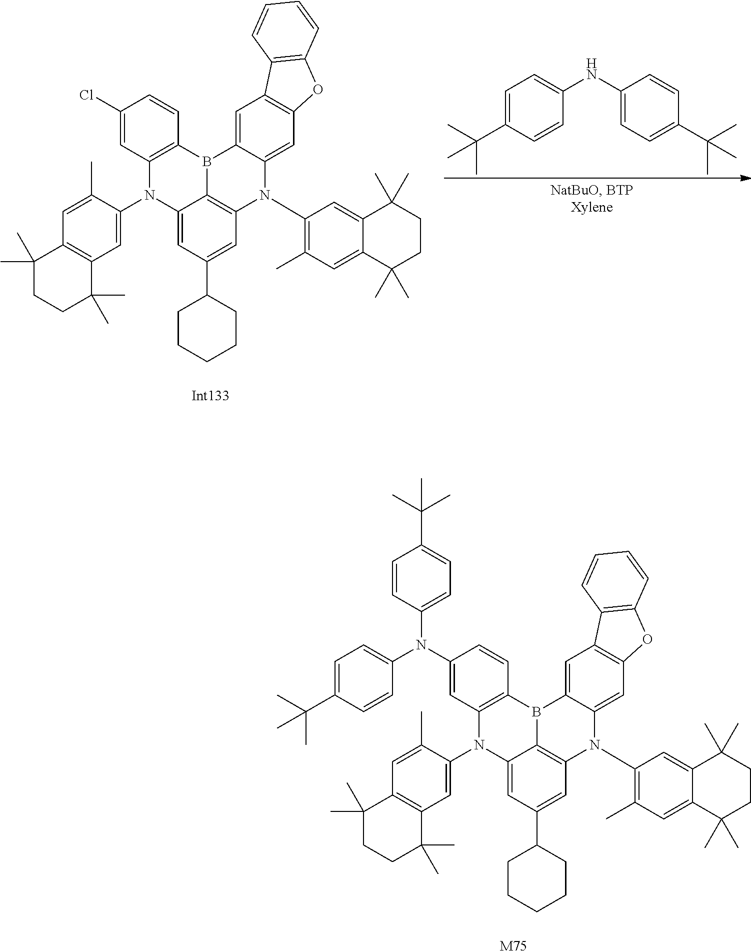

### 1) Synthesis of Int131

Int131 (46 g, yield 73%) was obtained using the same method and equivalents as in Synthesis of Int116 except that A7 and N-(3,5,5,8,8-pentamethyl-5,6,7,8-tetrahydronaphthalen-2-yl)dibenzo[b,d]furan-3-amine were used under a nitrogen atmosphere. MS[M+H]+=577

### 2) Synthesis of Int132

Int132 (31 g, yield 69%) was obtained using the same method and equivalents as in Synthesis of Int117 except that Int131 was used under a nitrogen atmosphere. MS[M+H]+=868

### 3) Synthesis of Int133

After introducing Int132 (25 g) and boron triiodide (19.2 g) to 1,2-dichlorobenzene (250 ml), the mixture was stirred for 8 hours at 160° C. After the reaction was finished, the result was extracted and then recrystallized to obtain Int133 (7.6 g, yield 30%). MS[M+H]+=876

### 4) Synthesis of Compound M75

After introducing Int133 (7 g), bis(4-(tert-butyl)phenyl)amine (2.3 g), sodium-tert-butoxide (1.6 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M75 (6.4 g, yield 71%). MS[M+H]+=1121

### Synthesis Example 76. Synthesis of Compound M76

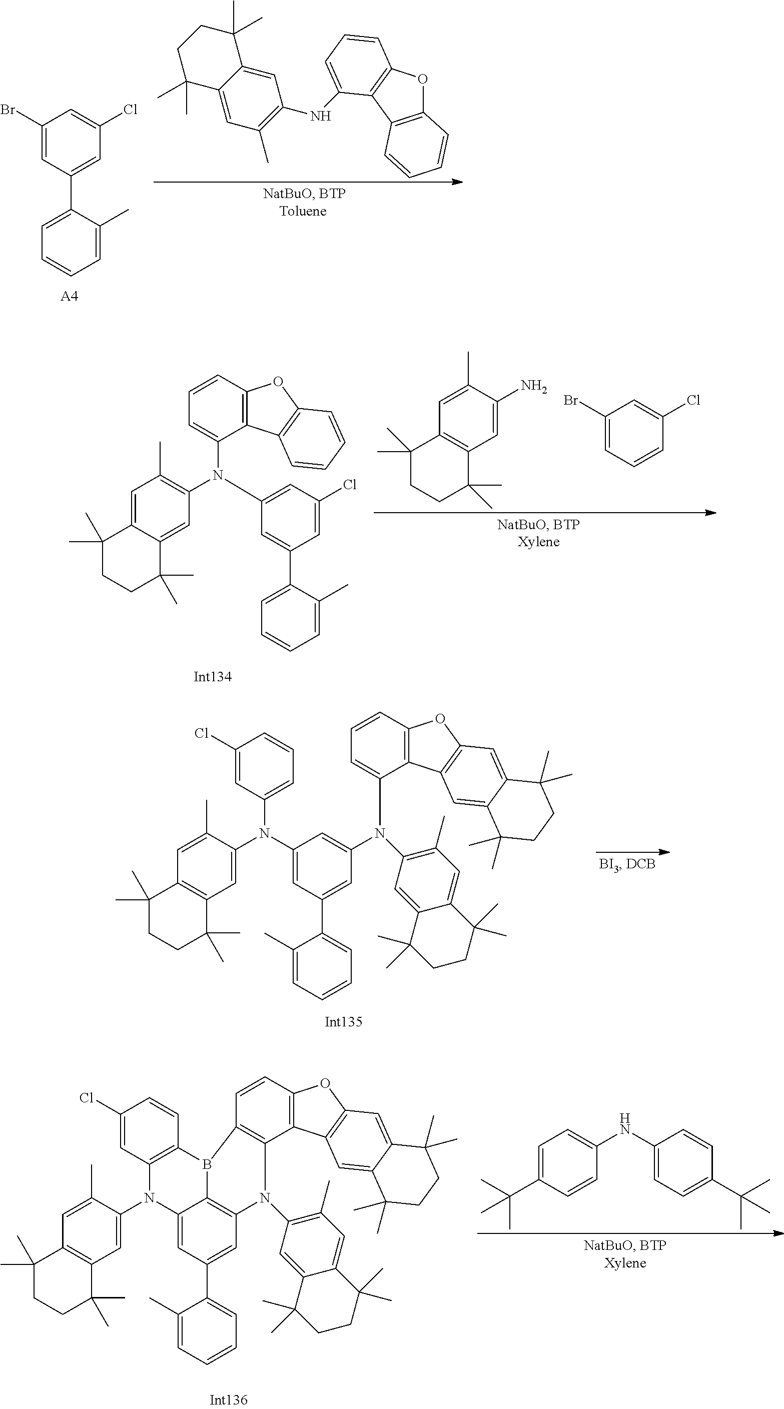

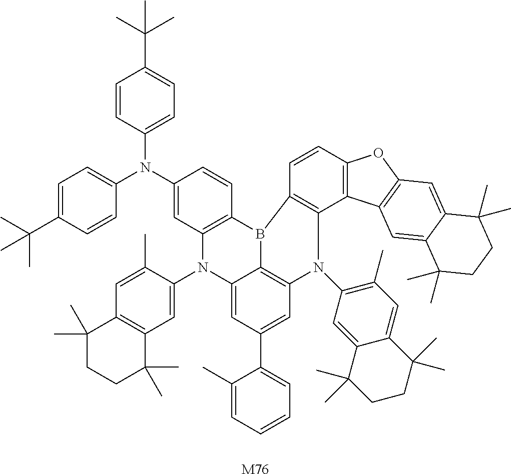

### 1) Synthesis of Int134

Int134 (46 g, yield 74%) was obtained using the same method and equivalents as in Synthesis of Int116 except that A4 and N-(3,5,5,8,8-pentamethyl-5,6,7,8-tetrahydronaphthalen-2-yl)dibenzo[b,d]furan-1-amine were used under a nitrogen atmosphere. MS[M+H]+=585

### 2) Synthesis of Int135

Int135 (37 g, yield 73%) was obtained using the same method and equivalents as in Synthesis of Int117 except that Int134 was used under a nitrogen atmosphere. MS[M+H]+=986

### 3) Synthesis of Int136

After introducing Int135 (25 g) and boron triiodide (16.8 g) to 1,2-dichlorobenzene (250 ml), the mixture was stirred for 8 hours at 160° C. After the reaction was finished, the result was extracted and then recrystallized to obtain Int136 (7.5 g, yield 30%). MS[M+H]+=994

### 4) Synthesis of Compound M76

After introducing Int136 (7 g), bis(4-(tert-butyl)phenyl)amine (2.0 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M76 (6.6 g, yield 76%). MS[M+H]+=1239

### Synthesis Example 77. Synthesis of Compound M77

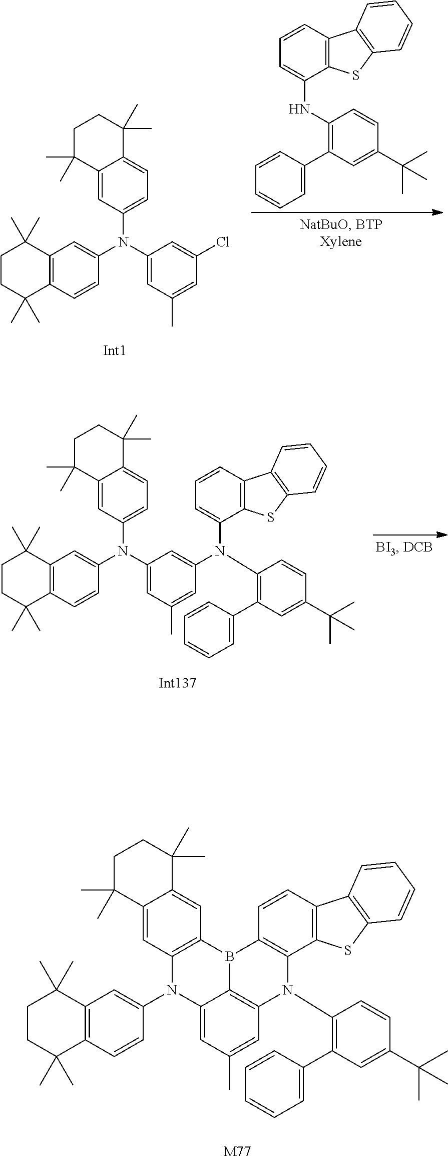 [SMILES: Cc1cc(Cl)cc(N(c2ccc3c(c2)C(C)(C)CCC3(C)C)c2ccc3c(c2)C(C)(C)CCC3(C)C)c1 ; CC(C)(C)c1ccc(Nc2cccc3c2sc2ccccc23)c(-c2ccccc2)c1 ; Cc1cc(N(c2ccc3c(c2)C(C)(C)CCC3(C)C)c2ccc3c(c2)C(C)(C)CCC3(C)C)cc(N(c2ccc(C(C)(C)C)cc2-c2ccccc2)c2cccc3c2sc2ccccc23)c1 ; Cc1cc2c3c(c1)N(c1ccc(C(C)(C)C)cc1-c1ccccc1)c1c(ccc4c1sc1ccccc14)B3c1cc3c(cc1N2c1ccc2c(c1)C(C)(C)CCC2(C)C)C(C)(C)CCC3(C)C ; "M77"]

### 1) Synthesis of Int137

Int137 (36 g, yield 70%) was obtained using the same method and equivalents as in Synthesis of Int2 except that Int1 and N-(5-(tert-butyl)-[1,1′-biphenyl]-2-yl)dibenzo[b,d]-thiophen-4-amine were used under a nitrogen atmosphere. MS[M+H]+=886

### 2) Synthesis of Compound M77

After introducing Int137 (25 g) and boron triiodide (18.8 g) to 1,2-dichlorobenzene (250 ml), the mixture was stirred for 8 hours at 160° C. After the reaction was finished, the result was extracted and then recrystallized to obtain Compound M77 (7.6 g, yield 30%). MS[M+H]+=894

### Synthesis Example 78. Synthesis of Compound M78

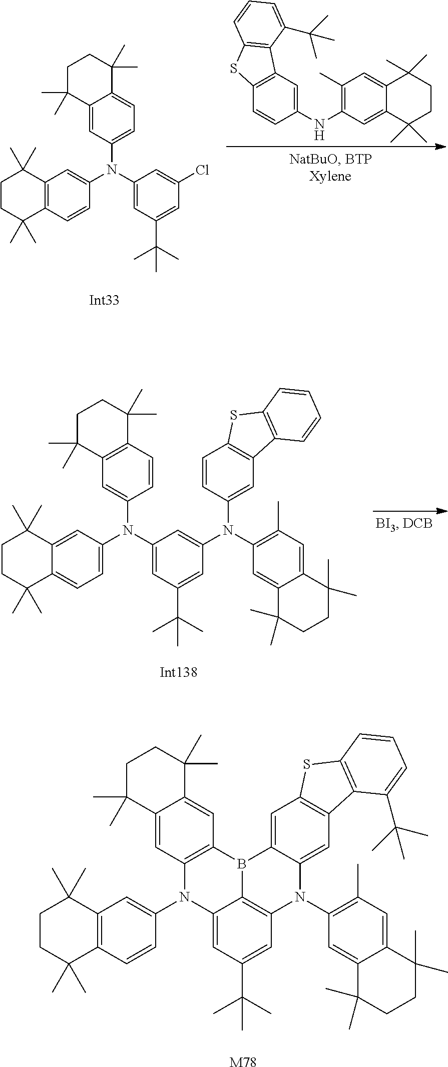

### 1) Synthesis of Int138

Int138 (39 g, yield 74%) was obtained using the same method and equivalents as in Synthesis of Int2 except that Int33 and 9-(tert-butyl)-N-(3,5,5,8,8-pentamethyl-5,6,7,8-tetrahydronaphthalen-2-yl)dibenzo[b,d]thiophen-2-amine were used under a nitrogen atmosphere. MS[M+H]+=976

### 2) Synthesis of Compound M78

After introducing Int138 (25 g) and boron triiodide (17.1 g) to 1,2-dichlorobenzene (250 ml), the mixture was stirred for 8 hours at 160° C. After the reaction was finished, the result was extracted and then recrystallized to obtain Compound M78 (7.7 g, yield 31%). MS[M+H]+=984

### Synthesis Example 79. Synthesis of Compound M79

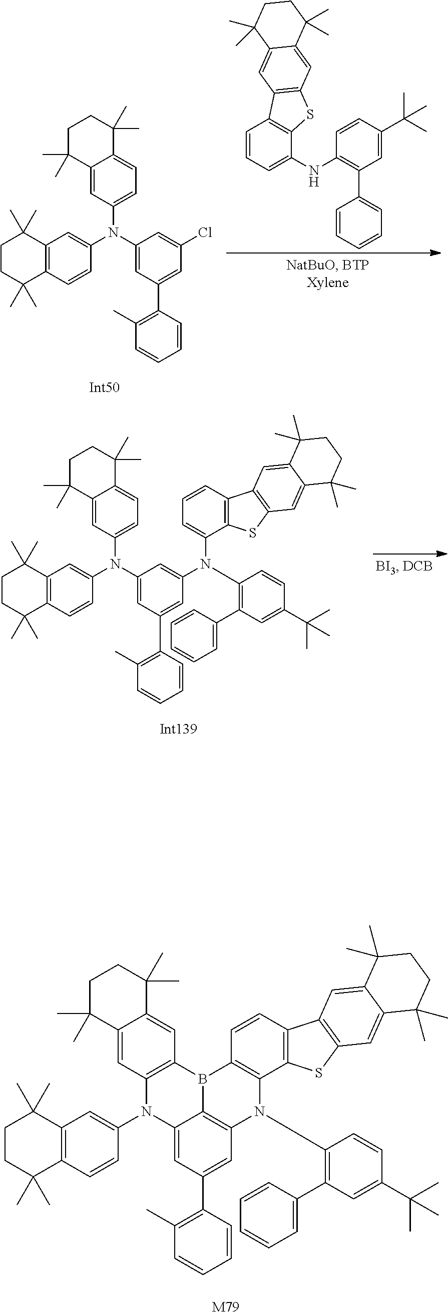

### 1) Synthesis of Int139

Int139 (38 g, yield 70%) was obtained using the same method and equivalents as in Synthesis of Int2 except that Int50 and N-(5-(tert-butyl)-[1,1′-biphenyl]-2-yl)-7,7,10,10-tetramethyl-7,8,9,10-tetrahydrobenzo[b]naphtho[2,3-d]thiophen-4-amine were used under a nitrogen atmosphere. MS[M+H]+=1072

### 2) Synthesis of Compound M79

After introducing Int139 (25 g) and boron triiodide (17.1 g) to 1,2-dichlorobenzene (250 ml), the mixture was stirred for 8 hours at 160° C. After the reaction was finished, the result was extracted and then recrystallized to obtain Compound M79 (7.4 g, yield 29%). MS[M+H]+=1080

### Synthesis Example 80. Synthesis of Compound M80

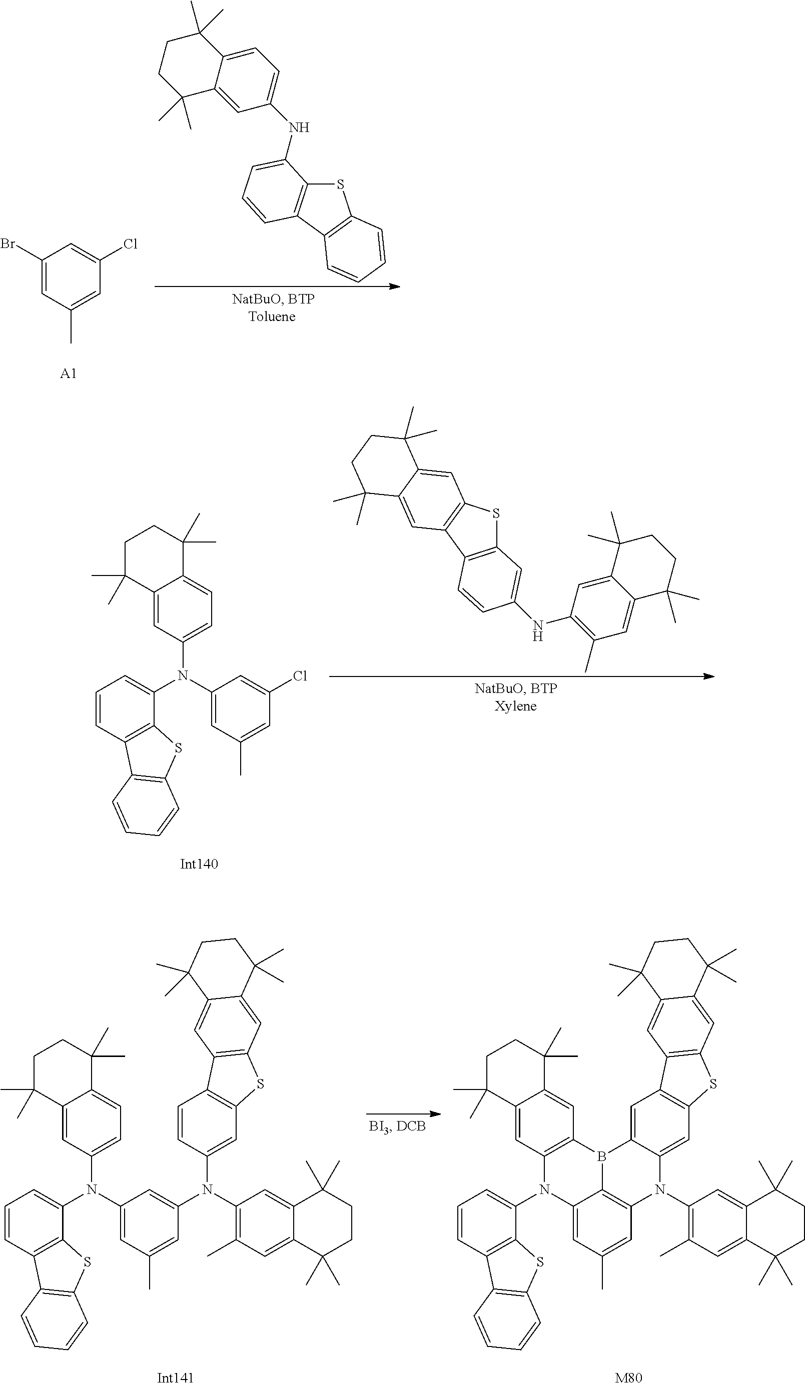

### 1) Synthesis of Int140

Int140 (51 g, yield 68%) was obtained using the same method and equivalents as in Synthesis of Int1 except that A1 and N-(5,5,8,8-tetramethyl-5,6,7,8-tetrahydronaphthalen-2-yl)dibenzo[b,d]thiophen-4-amine were used under a nitrogen atmosphere. MS[M+H]+=510

### 2) Synthesis of Int141

Int141 (41 g, yield 71%) was obtained using the same method and equivalents as in Synthesis of Int2 except that Int140 and 7,7,10,10-tetramethyl-N-(3,5,5,8,8-pentamethyl-5,6,7,8-tetrahydronaphthalen-2-yl)-7,8,9,10-tetrahydrobenzo[b]naphtho[2,3-d]thiophen-3-amine were used under a nitrogen atmosphere. MS[M+H]+=984

### 3) Synthesis of Compound M80

After introducing Int141 (25 g) and boron triiodide (16.8 g) to 1,2-dichlorobenzene (250 ml), the mixture was stirred for 8 hours at 160° C. After the reaction was finished, the result was extracted and then recrystallized to obtain Compound M80 (7.4 g, yield 29%). MS[M+H]+=992

### Synthesis Example 81. Synthesis of Compound M81

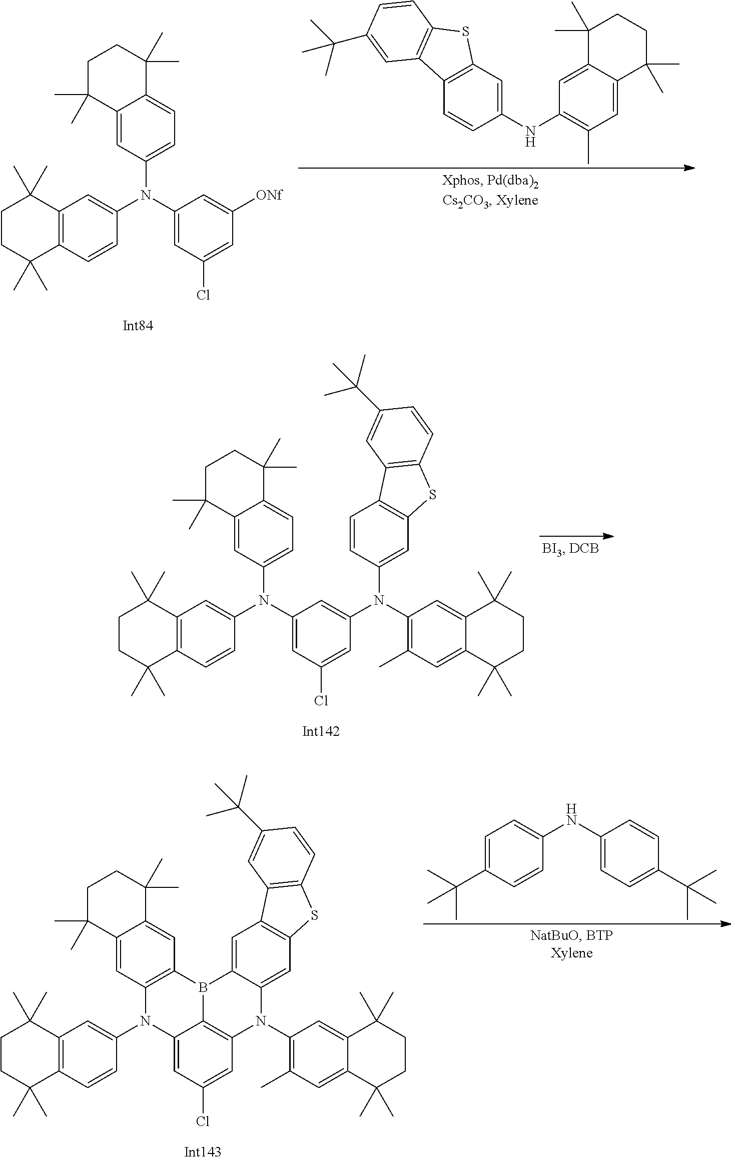

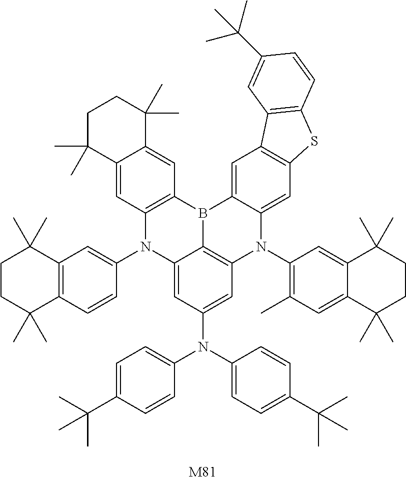 [SMILES: Cc1cc2c(cc1N1c3cc4sc5ccc(C(C)(C)C)cc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C ; "M81"]

### 1) Synthesis of Int142

Int142 (38 g, yield 80%) was obtained using the same method and equivalents as in Synthesis of Int85 except that Int84 and 8-(tert-butyl)-N-(3,5,5,8,8-pentamethyl-5,6,7,8-tetrahydronaphthalen-2-yl)dibenzo[b,d]thiophen-3-amine were used under a nitrogen atmosphere. MS[M+H]+=954

### 2) Synthesis of Int143

After introducing Int142 (25 g) and boron triiodide (17.4 g) to 1,2-dichlorobenzene (250 ml), the mixture was stirred for 4 hours at 160° C. After the reaction was finished, the result was extracted and then recrystallized to obtain Int143 (7.4 g, yield 29%). MS[M+H]+=962

### 3) Synthesis of Compound M81

After introducing Int143 (7 g), bis(4-(tert-butyl)phenyl)amine (2.1 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M81 (6.4 g, yield 73%). MS[M+H]+=1207

### Synthesis Example 82. Synthesis of Compound M82

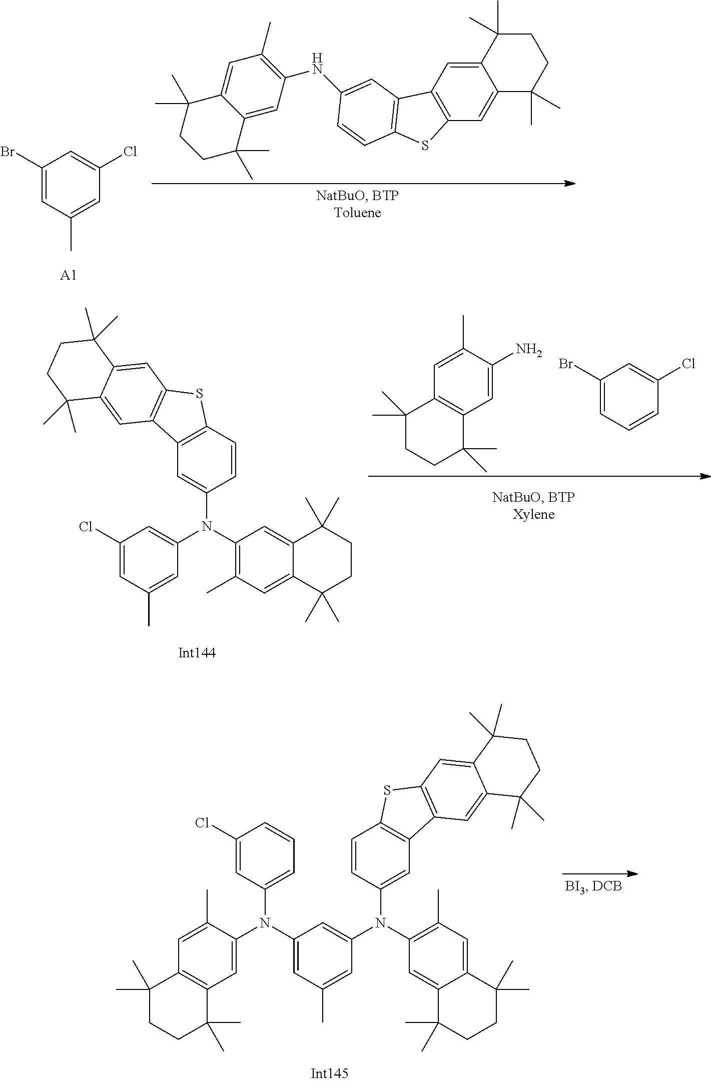

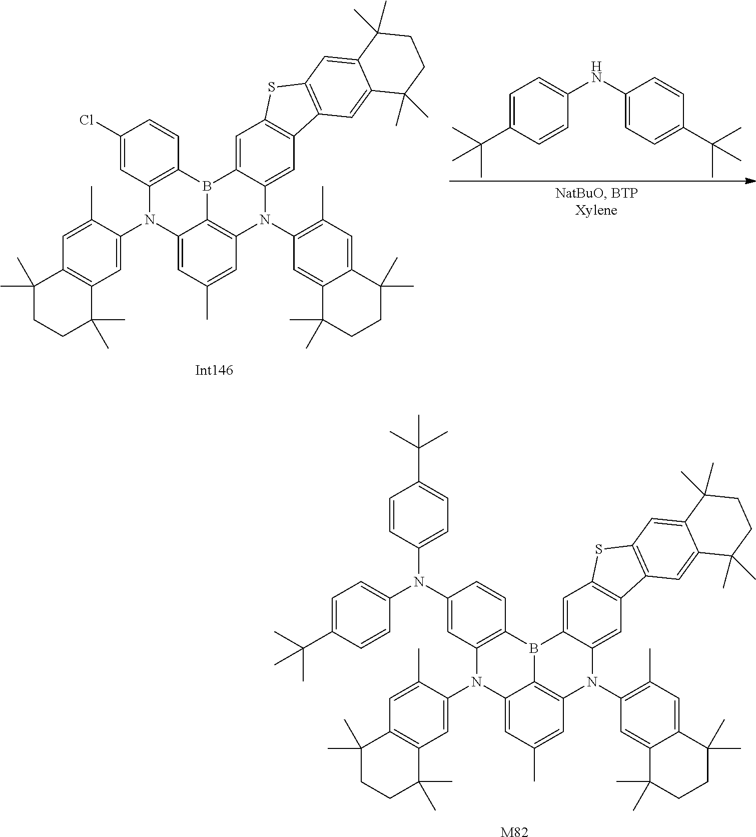

### 1) Synthesis of Int144

Int144 (65 g, yield 70%) was obtained using the same method and equivalents as in Synthesis of Int116 except that A1 and 7,7,10,10-tetramethyl-N-(3,5,5,8,8-pentamethyl-5,6,7,8-tetrahydronaphthalen-2-yl)-7,8,9,10-tetrahydrobenzo[b]naphtho[2,3-d]thiophen-2-amine were used under a nitrogen atmosphere. MS[M+H]+=635

### 2) Synthesis of Int145

Int145 (33 g, yield 75%) was obtained using the same method and equivalents as in Synthesis of Int117 except that Int144 was used under a nitrogen atmosphere. MS[M+H]+=926

### 3) Synthesis of Int146

After introducing Int145 (25 g) and boron triiodide (18.0 g) to 1,2-dichlorobenzene (250 ml), the mixture was stirred for 8 hours at 160° C. After the reaction was finished, the result was extracted and then recrystallized to obtain Int146 (7.6 g, yield 30%). MS[M+H]+=934

### 4) Synthesis of Compound M82

After introducing Int146 (7 g), bis(4-(tert-butyl)phenyl)amine (2.2 g), sodium-tert-butoxide (1.5 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M82 (6.5 g, yield 74%). MS[M+H]+=1179

### Synthesis Example 83. Synthesis of Compound M83

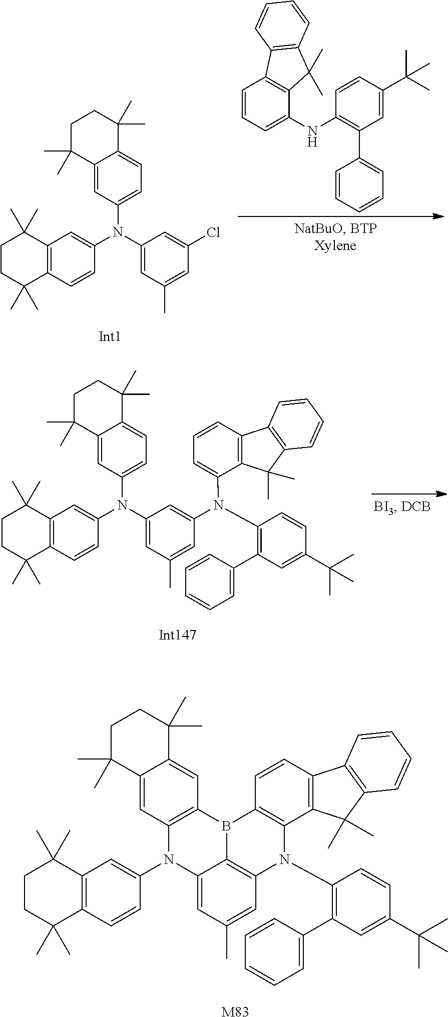 [SMILES: Cc1cc(Cl)cc(N(c2ccc3c(c2)C(C)(C)CCC3(C)C)c2ccc3c(c2)C(C)(C)CCC3(C)C)c1 ; CC(C)(C)c1ccc(Nc2cccc3c2C(C)(C)c2ccccc2-3)c(-c2ccccc2)c1 ; Cc1cc(N(c2ccc3c(c2)C(C)(C)CCC3(C)C)c2ccc3c(c2)C(C)(C)CCC3(C)C)cc(N(c2ccc(C(C)(C)C)cc2-c2ccccc2)c2cccc3c2C(C)(C)c2ccccc2-3)c1 ; Cc1cc2c3c(c1)N(c1ccc(C(C)(C)C)cc1-c1ccccc1)c1c(ccc4c1C(C)(C)c1ccccc1-4)B3c1cc3c(cc1N2c1ccc2c(c1)C(C)(C)CCC2(C)C)C(C)(C)CCC3(C)C ; "M83"]

### 1) Synthesis of Int147

Int147 (35 g, yield 67%) was obtained using the same method and equivalents as in Synthesis of Int2 except that Int1 and N-(5-(tert-butyl)-[1,1′-biphenyl]-2-yl)-9,9-dimethyl-9H-fluoren-1-amine were used under a nitrogen atmosphere. MS[M+H]+=896

### 2) Synthesis of Compound M83

After introducing Int147 (25 g) and boron triiodide (18.6 g) to 1,2-dichlorobenzene (250 ml), the mixture was stirred for 8 hours at 160° C. After the reaction was finished, the result was extracted and then recrystallized to obtain Compound M83 (7.5 g, yield 30%). MS[M+H]+=904

### Synthesis Example 84. Synthesis of Compound M84

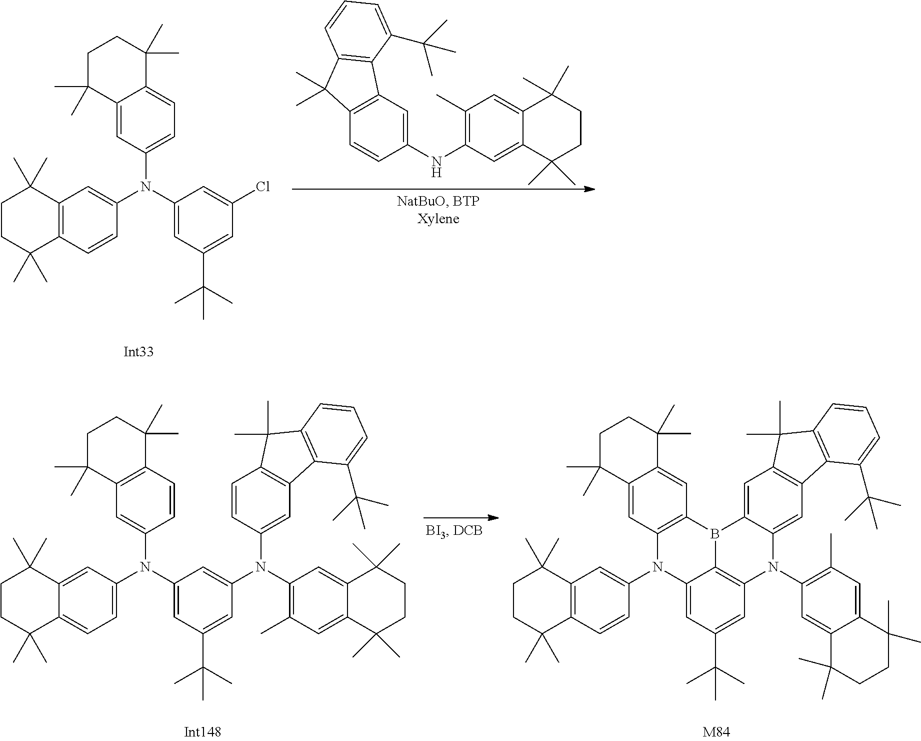

### 1) Synthesis of Int148

Int148 (41 g, yield 77%) was obtained using the same method and equivalents as in Synthesis of Int2 except that Int33 and 5-(tert-butyl)-9,9-dimethyl-N-(3,5,5,8,8-pentamethyl-5,6,7,8-tetrahydronaphthalen-2-yl)-9H-fluoren-3-amine were used under a nitrogen atmosphere. MS[M+H]+=986

### 2) Synthesis of Compound M84

After introducing Int148 (25 g) and boron triiodide (16.9 g) to 1,2-dichlorobenzene (250 ml), the mixture was stirred for 8 hours at 160° C. After the reaction was finished, the result was extracted and then recrystallized to obtain Compound M84 (7.3 g, yield 29%). MS[M+H]+=994

### Synthesis Example 85. Synthesis of Compound M85

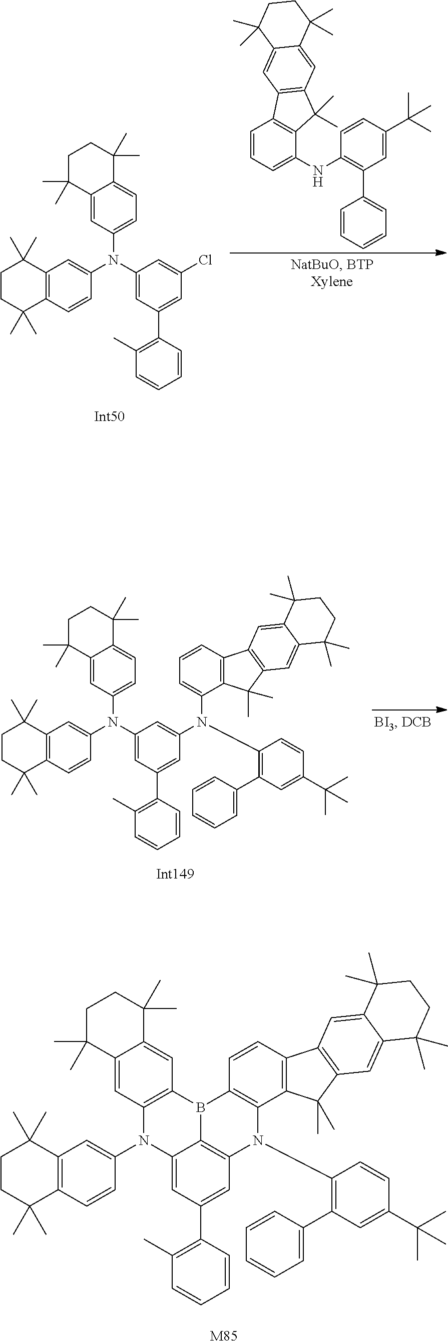

### 1) Synthesis of Int149

Int149 (40 g, yield 73%) was obtained using the same method and equivalents as in Synthesis of Int2 except that Int50 and N-(5-(tert-butyl)-[1,1′-biphenyl]-2-yl)-6,6,9,9,11,11-hexamethyl-7,8,9,11-tetrahydro-6H-benzo[b]fluoren-1-amine were used under a nitrogen atmosphere. MS[M+H]+=1082

### 2) Synthesis of Compound M85

After introducing Int149 (25 g) and boron triiodide (15.4 g) to 1,2-dichlorobenzene (250 ml), the mixture was stirred for 8 hours at 160° C. After the reaction was finished, the result was extracted and then recrystallized to obtain Compound M85 (7.4 g, yield 29%). MS[M+H]+=1090

### Synthesis Example 86. Synthesis of Compound M86

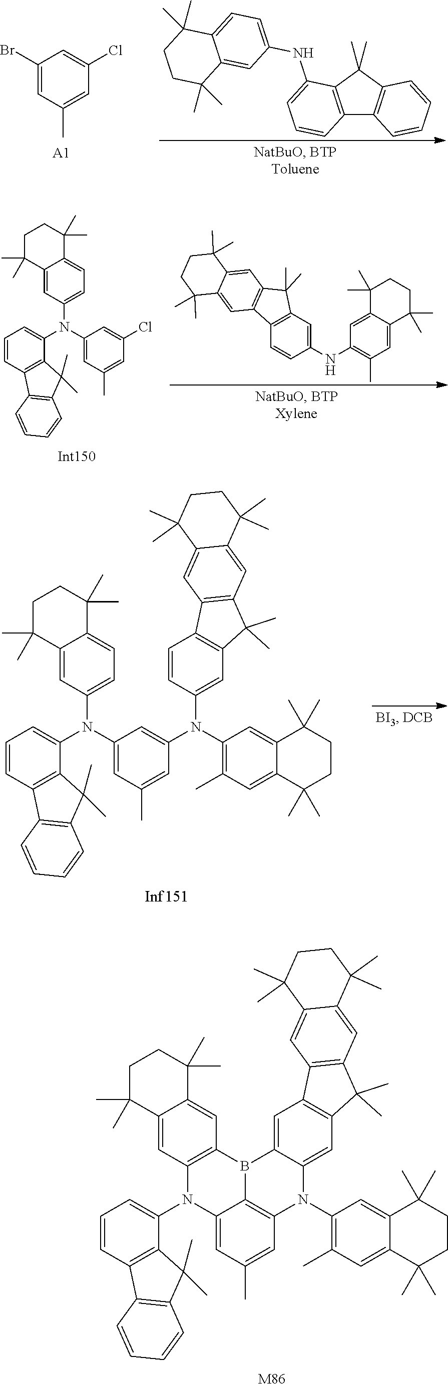

### 1) Synthesis of Int150

Int150 (54 g, yield 71%) was obtained using the same method and equivalents as in Synthesis of Int1 except that A1 and 9,9-dimethyl-N-(5,5,8,8-tetramethyl-5,6,7,8-tetrahydro-naphthalen-2-yl)-9H-fluoren-1-amine were used under a nitrogen atmosphere. MS[M+H]+=521

### 2) Synthesis of Int151

Int151 (42 g, yield 73%) was obtained using the same method and equivalents as in Synthesis of Int2 except that Int150 and 6,6,9,9,11,11-hexamethyl-N-(3,5,5,8,8-pentamethyl-5,6,7,8-tetrahydronaphthalen-2-yl)-7,8,9,11-tetrahydro-6H-benzo[b]fluoren-2-amine were used under a nitrogen atmosphere. MS[M+H]+=1004

### 3) Synthesis of Compound M86

After introducing Int151 (25 g) and boron triiodide (16.6 g) to 1,2-dichlorobenzene (250 ml), the mixture was stirred for 8 hours at 160° C. After the reaction was finished, the result was extracted and then recrystallized to obtain Compound M86 (7.5 g, yield 30%). MS[M+H]+=1012

### Synthesis Example 87. Synthesis of Compound M87

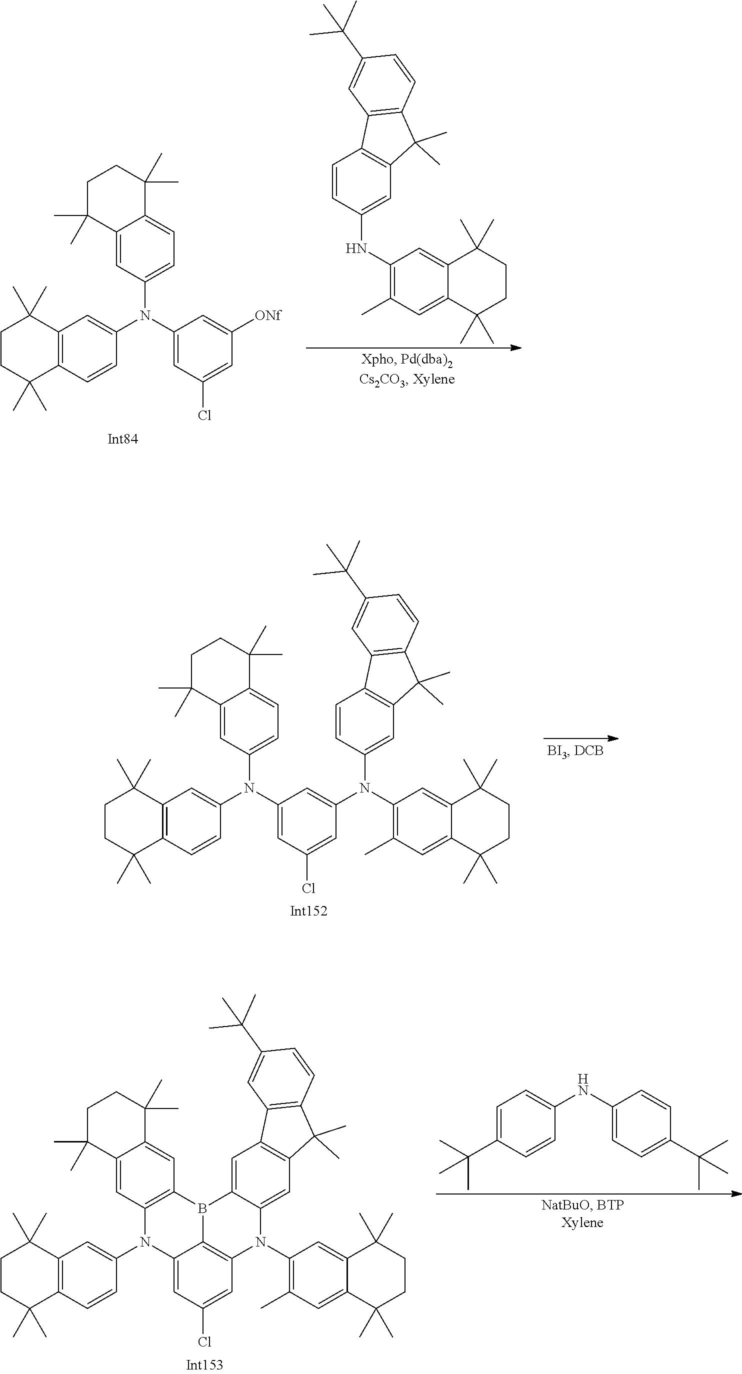

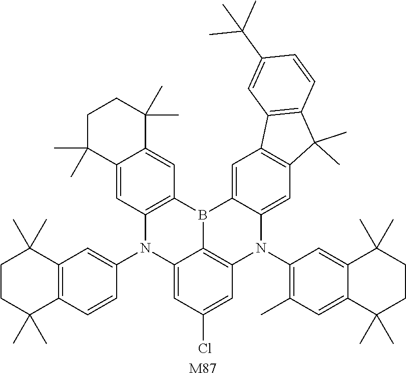

### 1) Synthesis of Int152

Int152 (37 g, yield 77%) was obtained using the same method and equivalents as in Synthesis of Int85 except that Int84 and 6-(tert-butyl)-9,9-dimethyl-N-(3,5,5,8,8-pentamethyl-5,6,7,8-tetrahydronaphthalen-2-yl)-9H-fluoren-2-amine were used under a nitrogen atmosphere. MS[M+H]+=964

### 2) Synthesis of Int153

After introducing Int152 (25 g) and boron triiodide (17.3 g) to 1,2-dichlorobenzene (250 ml), the mixture was stirred for 4 hours at 160° C. After the reaction was finished, the result was extracted and then recrystallized to obtain Int153 (7.6 g, yield 30%). MS[M+H]+=972

### 3) Synthesis of Compound M87

After introducing Int153 (7 g), bis(4-(tert-butyl)phenyl)amine (2.1 g), sodium-tert-butoxide (1.4 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M87 (6.6 g, yield 75%). MS[M+H]+=1217

### Synthesis Example 88. Synthesis of Compound M88

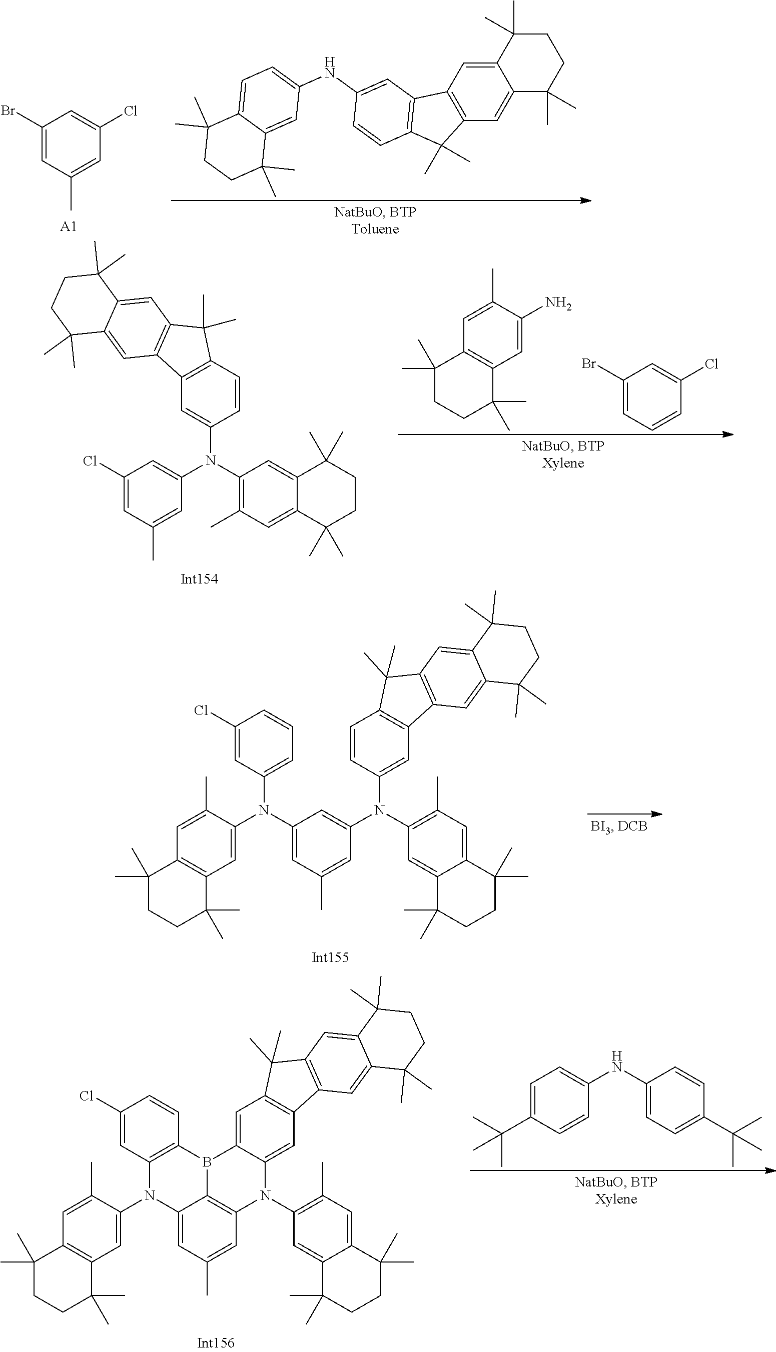

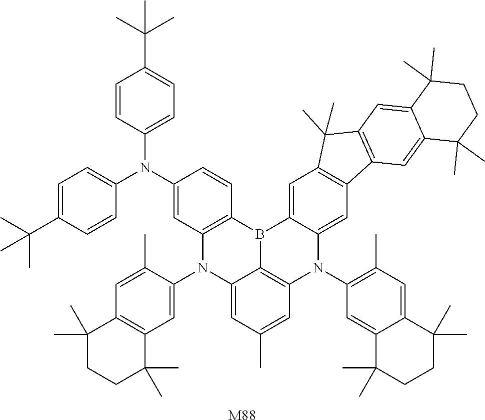 [SMILES: Cc1cc2c3c(c1)N(c1cc4c(cc1C)C(C)(C)CCC4(C)C)c1cc4c(cc1B3c1ccc(N(c3ccc(C(C)(C)C)cc3)c3ccc(C(C)(C)C)cc3)cc1N2c1cc2c(cc1C)C(C)(C)CCC2(C)C)C(C)(C)c1cc2c(cc1-4)C(C)(C)CCC2(C)C ; "M88"]

### 1) Synthesis of Int154

Int154 (62 g, yield 66%) was obtained using the same method and equivalents as in Synthesis of Int116 except that A1 and 6,6,9,9,11,11-hexamethyl-N-(3,5,5,8,8-pentamethyl-5,6,7,8-tetrahydronaphthalen-2-yl)-7,8,9,11-tetrahydro-6H-benzo[b]fluoren-3-amine were used under a nitrogen atmosphere. MS[M+H]+=645

### 2) Synthesis of Int155

Int155 (32 g, yield 73%) was obtained using the same method and equivalents as in Synthesis of Int117 except that Int154 was used under a nitrogen atmosphere. MS[M+H]+=936

### 3) Synthesis of Int156

After introducing Int155 (25 g) and boron triiodide (17.8 g) to 1,2-dichlorobenzene (250 ml), the mixture was stirred for 8 hours at 160° C. After the reaction was finished, the result was extracted and then recrystallized to obtain Int156 (7.7 g, yield 31%). MS[M+H]+=944

### 4) Synthesis of Compound M88

After introducing Int156 (7 g), bis(4-(tert-butyl)phenyl)amine (2.1 g), sodium-tert-butoxide (1.5 g) and bis(tri-tert-butylphosphine)palladium(0) (0.04 g) to toluene (100 ml) under a nitrogen atmosphere, the mixture was stirred for 6 hours under reflux. After the reaction was finished, the result was extracted and then recrystallized to obtain Compound M88 (6.7 g, yield 76%). MS[M+H]+=1189

### Experimental Example

### Example 1-1

A glass substrate on which indium tin oxide (ITO) was coated as a thin film to a thickness of 1,400 Å was placed in distilled water containing dissolved detergent and ultrasonically cleaned. Herein, a product of Fischer Co. was used as the detergent, and as the distilled water, distilled water filtered twice with a filter manufactured by Millipore Co. was used. After the ITO was cleaned for 30 minutes, ultrasonic cleaning was repeated twice using distilled water for 10 minutes. After the cleaning with distilled water was finished, the substrate was ultrasonically cleaned with solvents of isopropyl alcohol, acetone and methanol, then dried, and then transferred to a plasma cleaner. The substrate was cleaned for 5 minutes using oxygen plasma, and then transferred to a vacuum deposition apparatus.

On the transparent ITO electrode prepared as above, the following compounds HI-A and HAT-CN were thermal vacuum deposited to 650 Å and 50 Å, respectively, to form first and second hole injection layers. A hole transfer layer was formed on the hole injection layer by vacuum depositing the following compound HT-A to a thickness of 600 Å. On the hole transfer layer, an electron blocking layer was formed by vacuum depositing the following compound HT-B to a thickness of 50 Å.

Subsequently, a light emitting layer was formed on the electron blocking layer by vacuum depositing Compound M1 of the present disclosure as a blue light emitting dopant in 2 parts by weight with respect to 100 parts by weight of the light emitting layer, and the following compound BH1 as a host to a thickness of 200 Å.

Then, on the light emitting layer, the following Compound ET-A was vacuum deposited to 50 Å as a first electron transfer layer, and subsequently, the following compounds ET-B and LiQ were vacuum deposited in a weight ratio of 1:1 to a thickness of 360 Å to form a second electron transfer layer. An electron injection layer was formed on the second electron transfer layer by vacuum depositing LiQ to a thickness of 5 Å. On the electron injection layer, a cathode was formed by depositing aluminum and silver in a weight ratio of 10:1 to a thickness of 220 Å, and then depositing aluminum thereon to a thickness of 1000 Å.

In the above-described process, the deposition rates of the organic materials were maintained at 0.4 Å/sec to 0.9 Å/sec, the deposition rate of the aluminum of the cathode was maintained at 2 Å/sec, and the degree of vacuum during the deposition was maintained at 5×10⁻⁸ torr to 1×10⁻⁷ torr, and as a result, an organic light emitting device was manufactured.

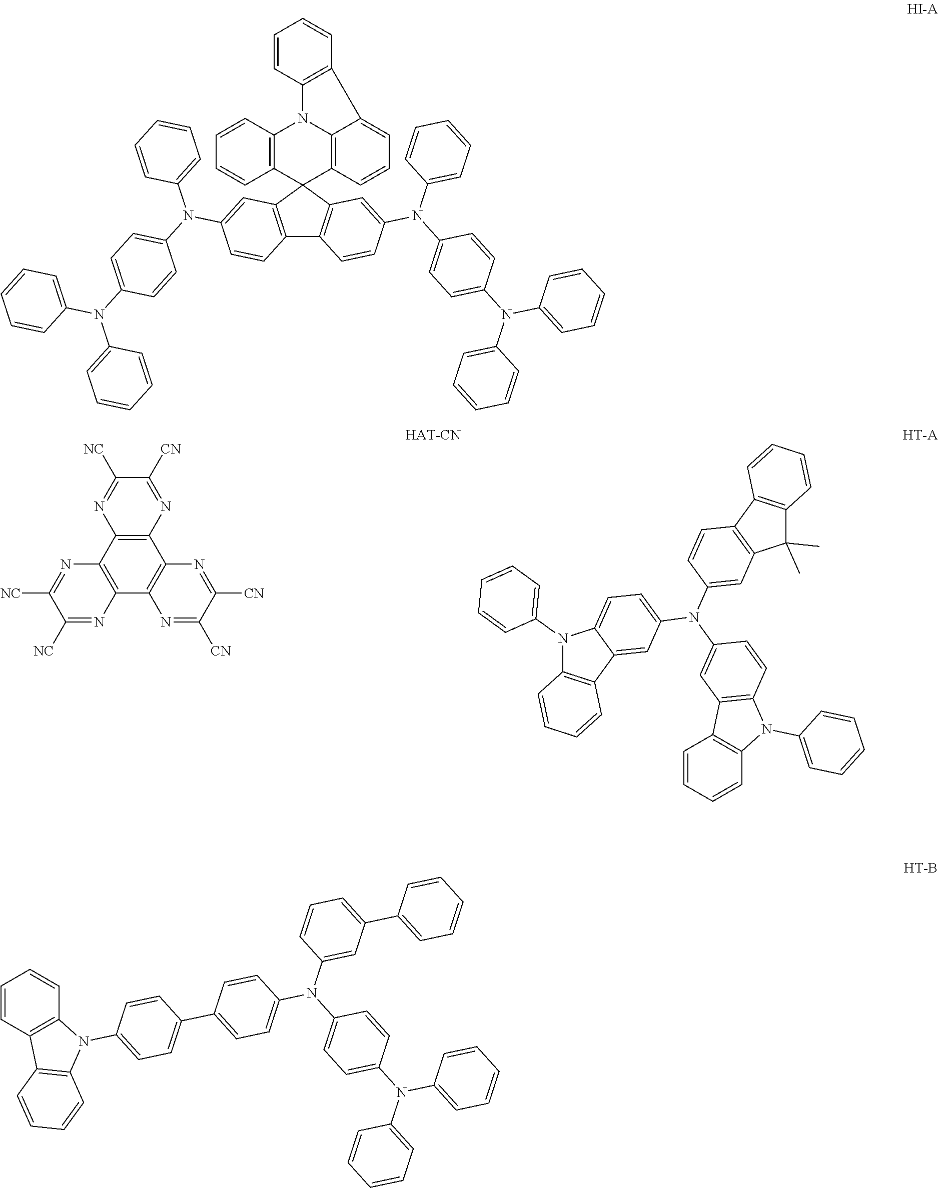

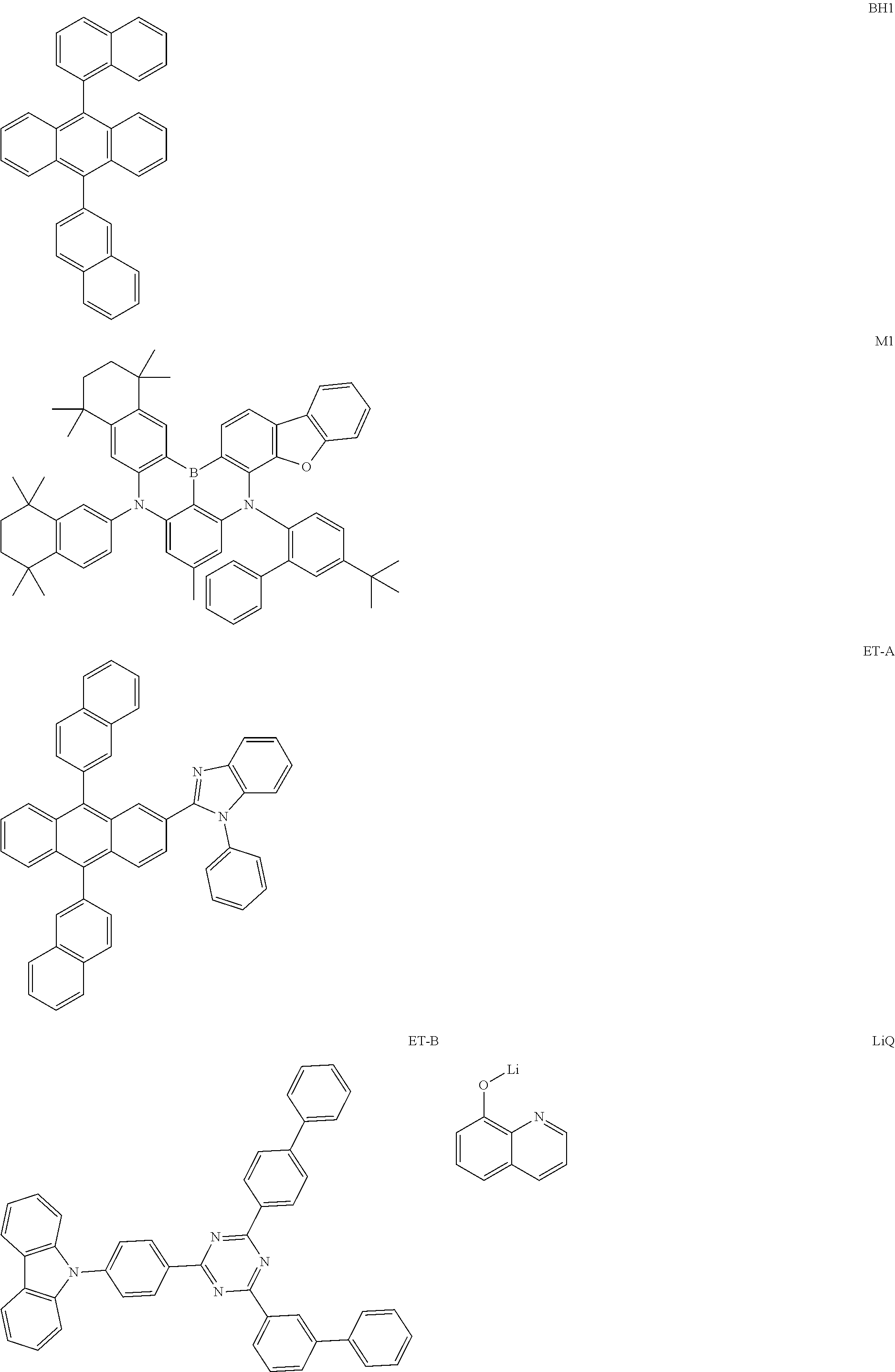

### Examples 1-2 to 1-88

Devices were manufactured in the same manner as in Example 1-1 except that compounds described in the following Table 1 were employed as the dopant of the light emitting layer.

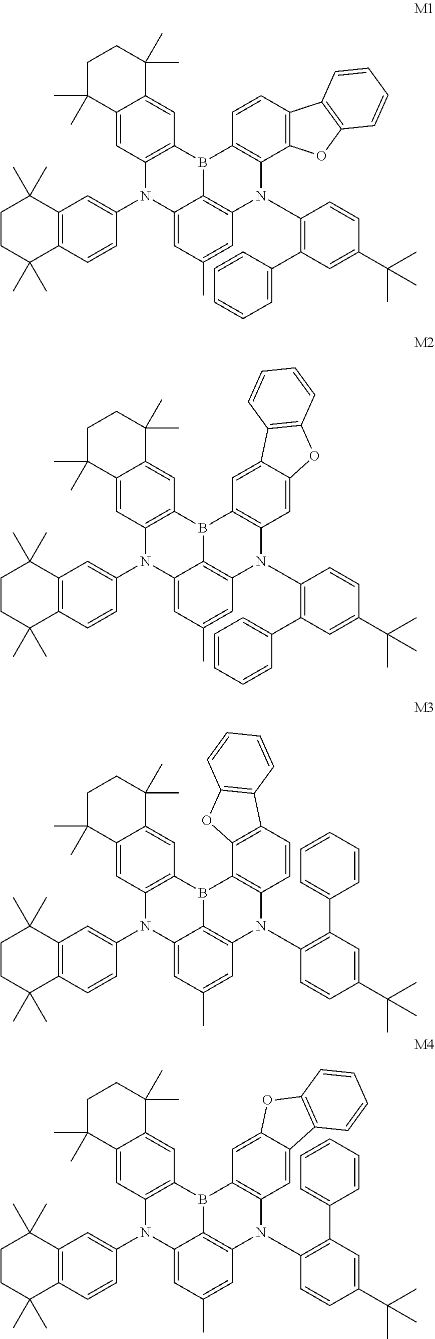 [SMILES: Cc1cc2c3c(c1)N(c1ccc(C(C)(C)C)cc1-c1ccccc1)c1c(ccc4c1oc1ccccc14)B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1ccccc14]

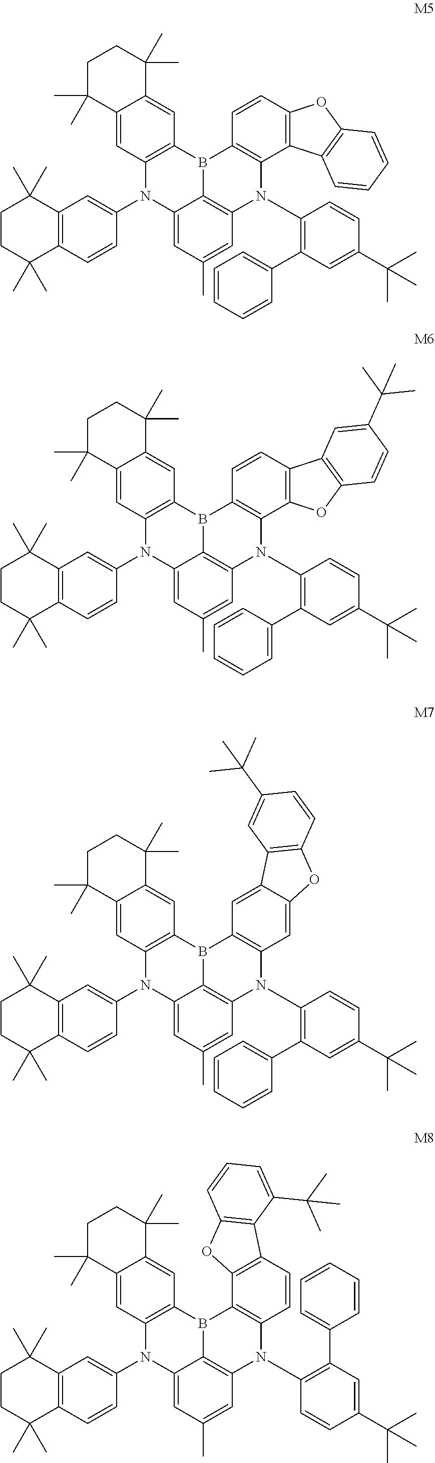

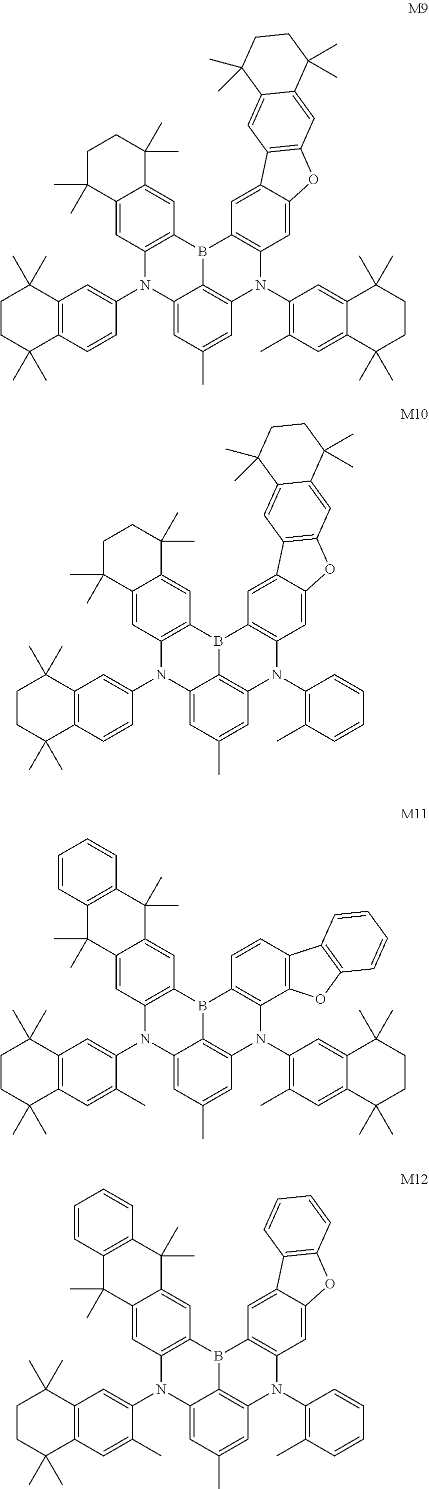 [SMILES: Cc1cc2c3c(c1)N(c1cc4c(cc1C)C(C)(C)CCC4(C)C)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1cc2c3c(c1)N(c1ccccc1C)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4oc5ccccc5c4cc1B3c1cc3c(cc1N2c1cc2c(cc1C)C(C)(C)CCC2(C)C)C(C)(C)c1ccccc1C3(C)C]

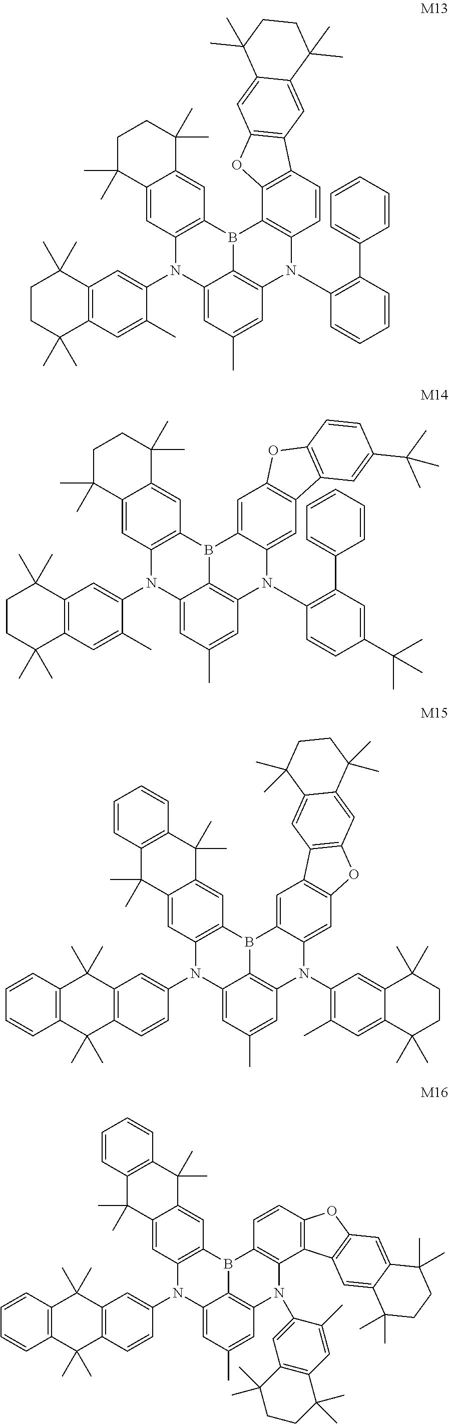

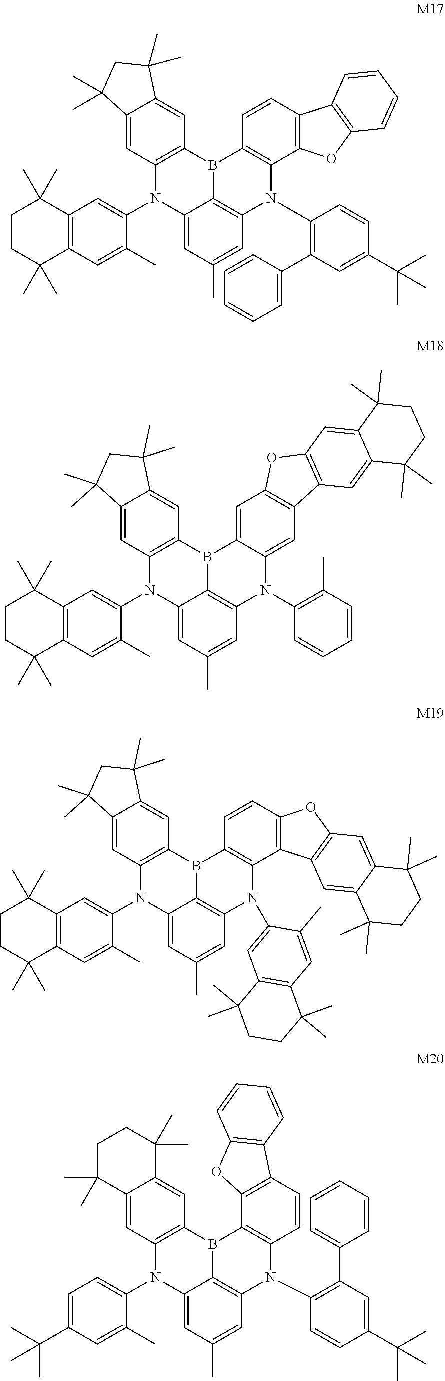

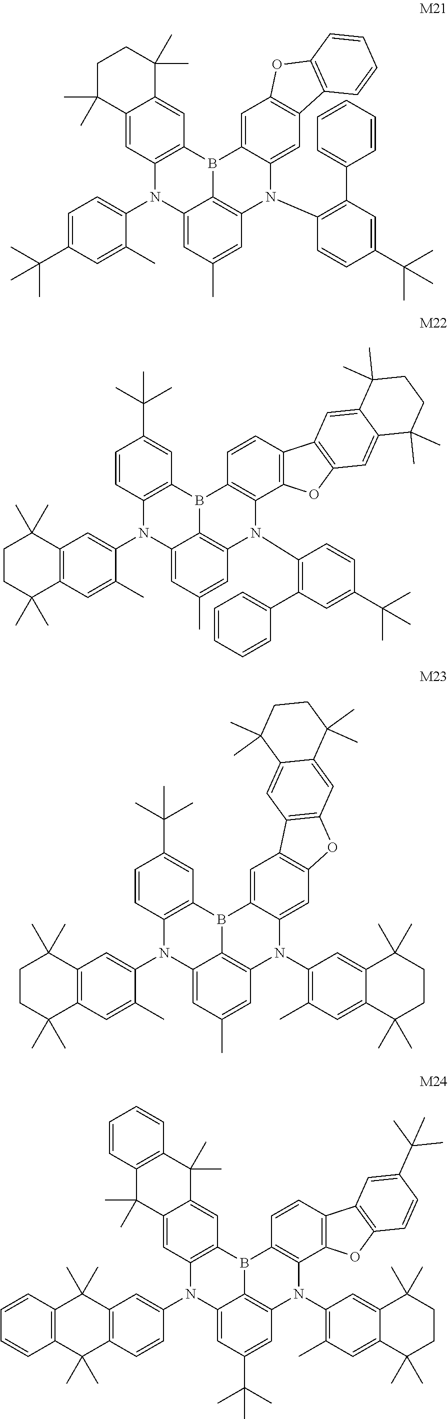

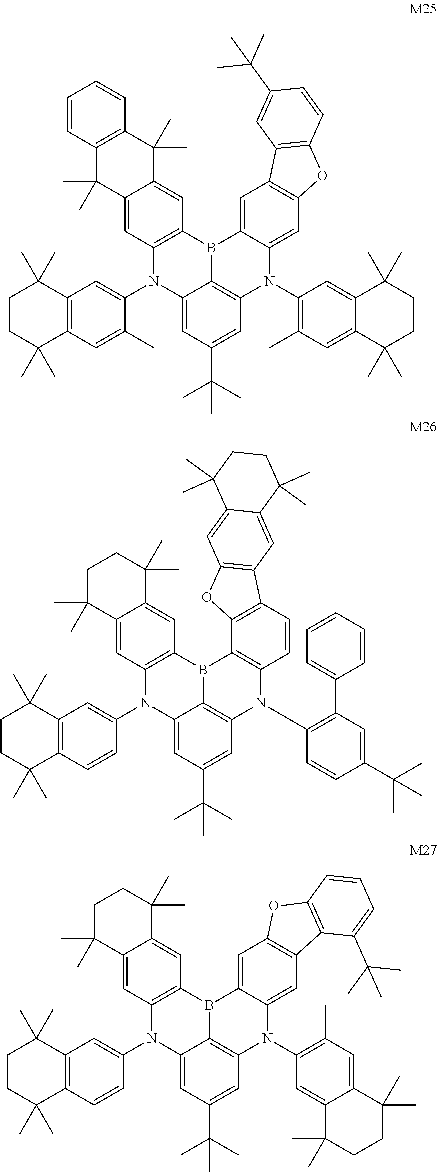

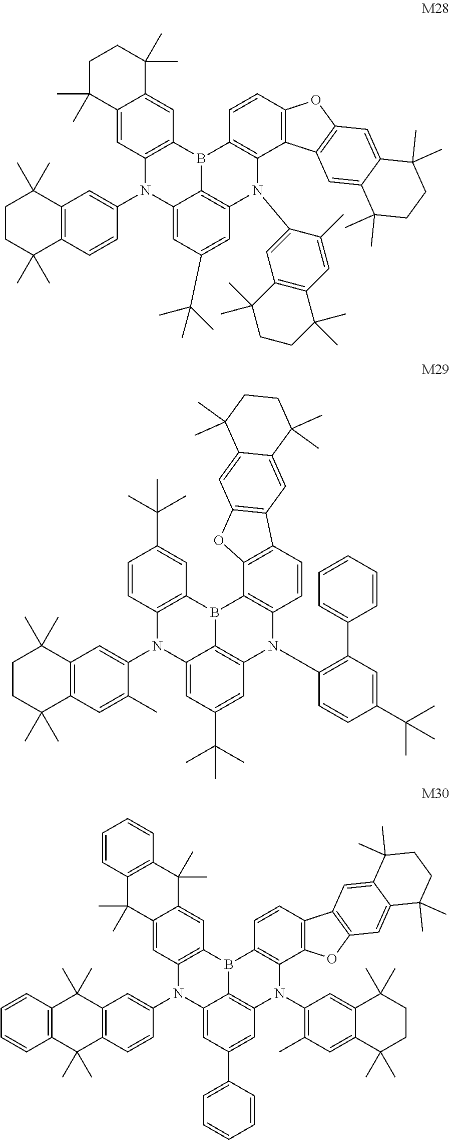 [SMILES: Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4oc5cc6c(cc5c4c31)C(C)(C)CCC6(C)C)C(C)(C)CCC2(C)C ; Cc1cc2c(cc1N1c3ccc(C(C)(C)C)cc3B3c4c1cc(C(C)(C)C)cc4N(c1ccc(C(C)(C)C)cc1-c1ccccc1)c1ccc4c(oc5cc6c(cc54)C(C)(C)CCC6(C)C)c13)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(oc5cc6c(cc54)C(C)(C)CCC6(C)C)c31)C(C)(C)CCC2(C)C]

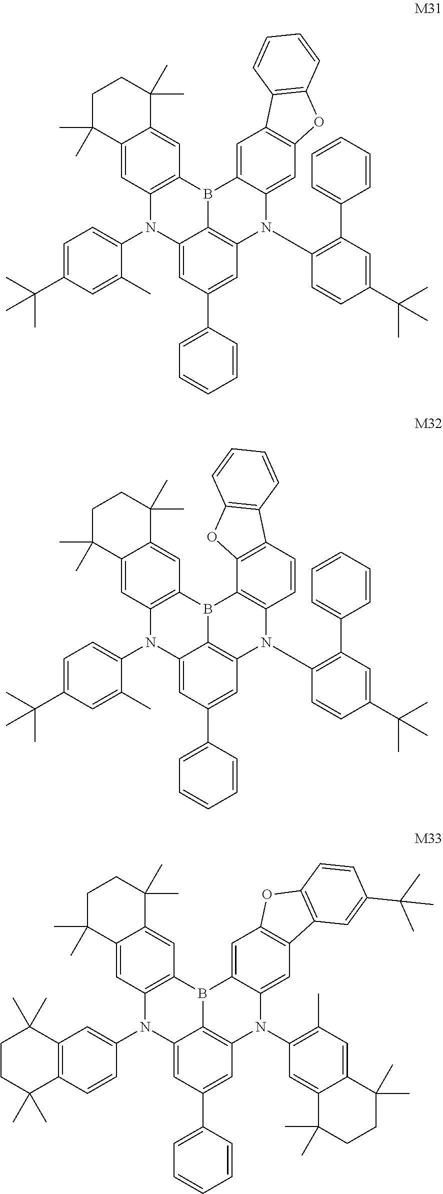

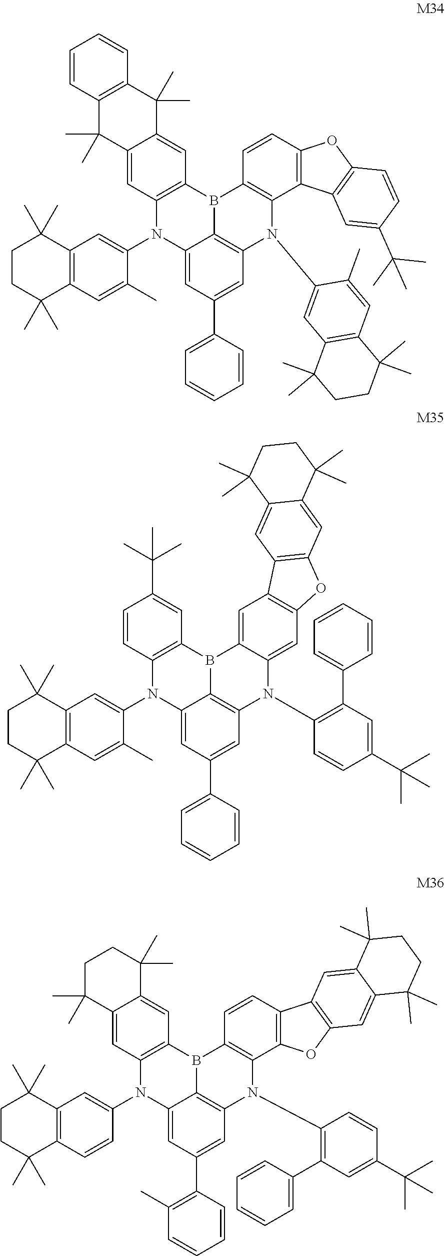 [SMILES: Cc1cc2c(cc1N1c3cc4c(cc3B3c5ccc6oc7ccc(C(C)(C)C)cc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6ccccc6)cc1c43)oc1cc3c(cc15)C(C)(C)CCC3(C)C)C(C)(C)CCC2(C)C ; Cc1ccccc1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C]

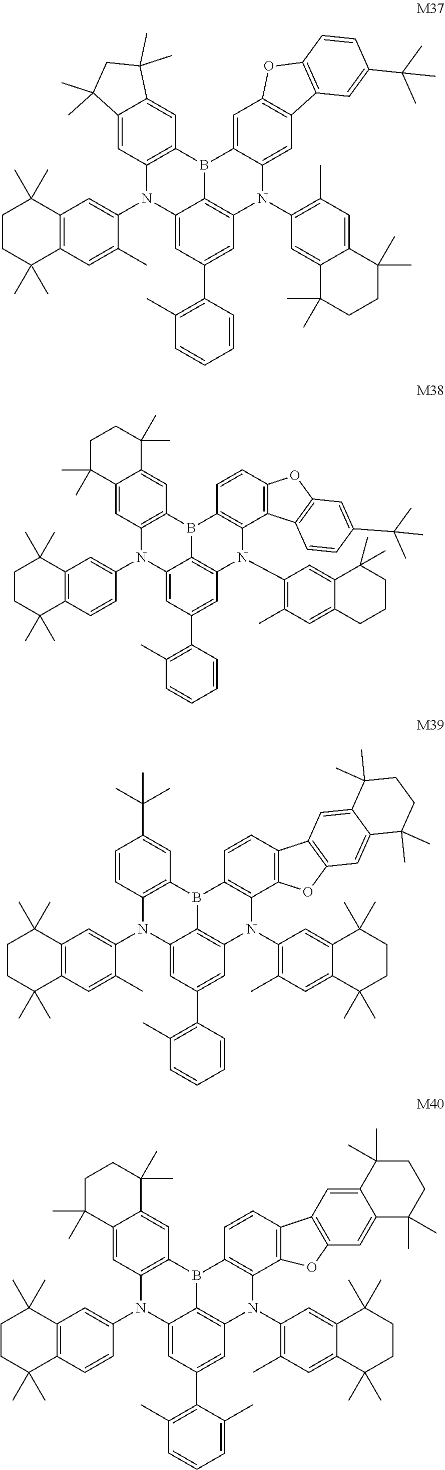

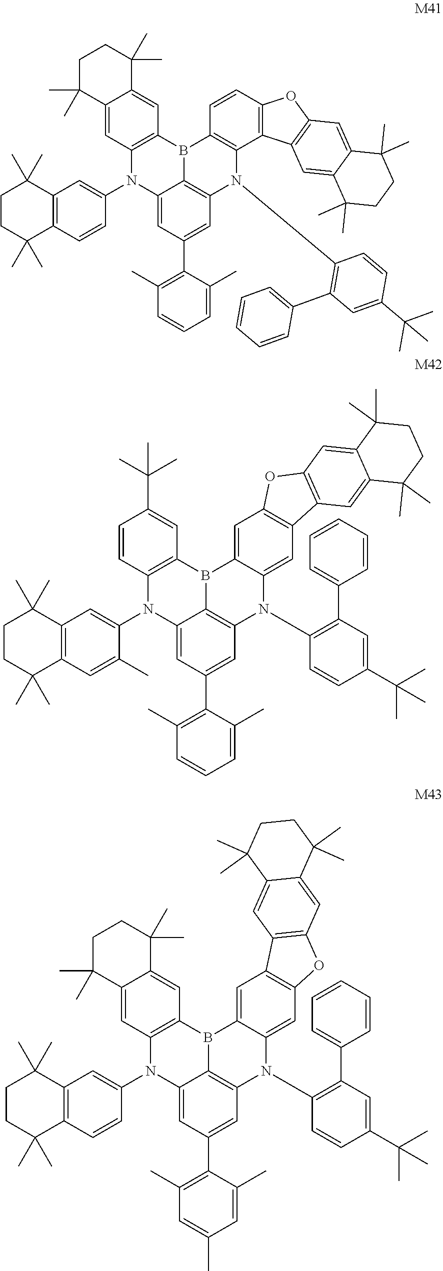

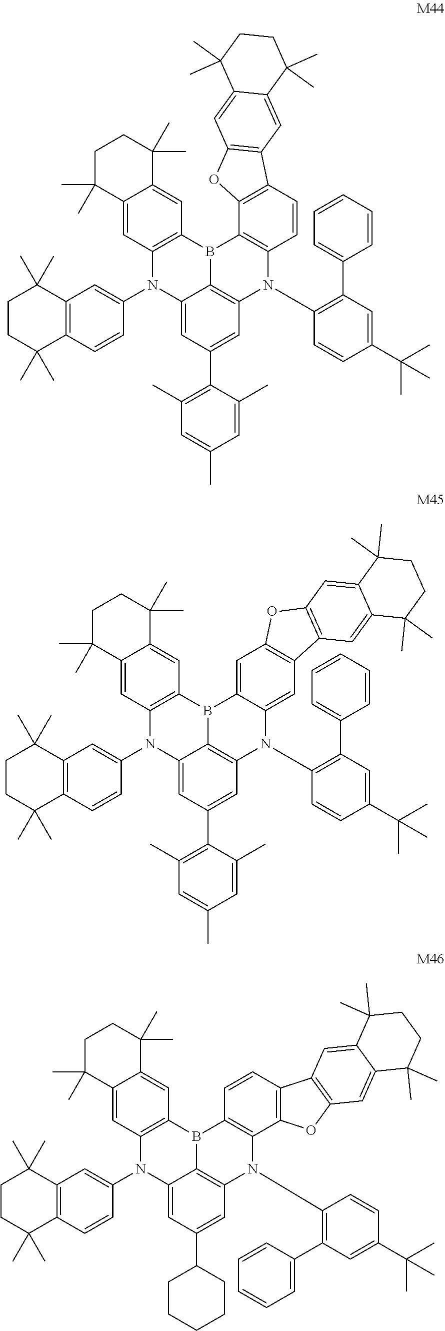 [SMILES: Cc1cc(C)c(-c2cc3c4c(c2)N(c2ccc(C(C)(C)C)cc2-c2ccccc2)c2ccc5c(oc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)c(C)c1 ; CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c32)c(-c2ccccc2)c1]

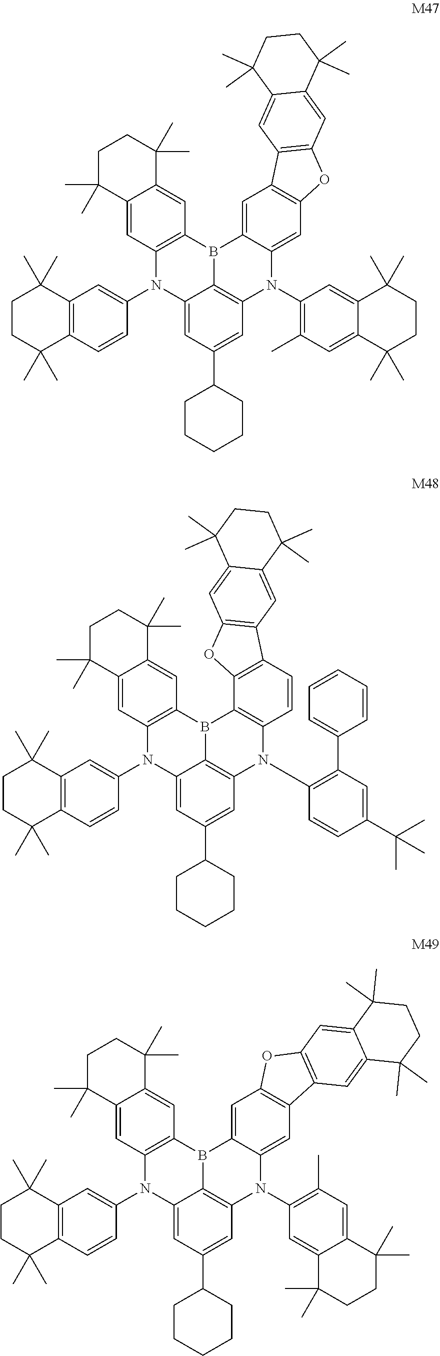 [SMILES: Cc1cc2c(cc1N1c3cc4oc5cc6c(cc5c4cc3B3c4cc5c(cc4N(c4ccc7c(c4)C(C)(C)CCC7(C)C)c4cc(C7CCCCC7)cc1c43)C(C)(C)CCC5(C)C)C(C)(C)CCC6(C)C)C(C)(C)CCC2(C)C ; CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3c2ccc2c3oc3cc4c(cc32)C(C)(C)CCC4(C)C)c(-c2ccccc2)c1 ; Cc1cc2c(cc1N1c3cc4c(cc3B3c5cc6c(cc5N(c5ccc7c(c5)C(C)(C)CCC7(C)C)c5cc(C7CCCCC7)cc1c53)C(C)(C)CCC6(C)C)oc1cc3c(cc14)C(C)(C)CCC3(C)C)C(C)(C)CCC2(C)C]

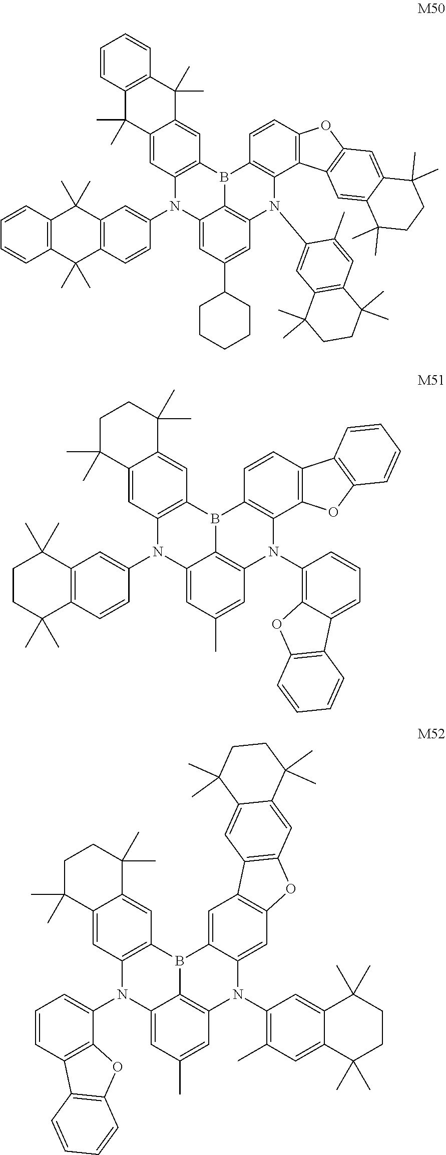

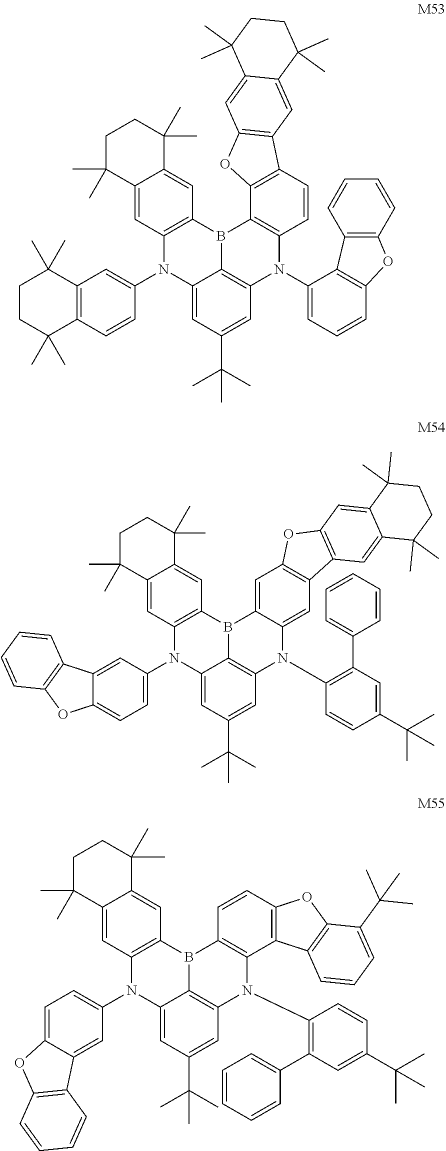 [SMILES: CC(C)(C)c1cc2c3c(c1)N(c1cccc4oc5ccccc5c14)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; CC(C)(C)c1ccc(N2c3cc4c(cc3B3c5cc6c(cc5N(c5ccc7oc8ccccc8c7c5)c5cc(C(C)(C)C)cc2c53)C(C)(C)CCC6(C)C)oc2cc3c(cc24)C(C)(C)CCC3(C)C)c(-c2ccccc2)c1 ; CC(C)(C)c1ccc(N2c3cc(C(C)(C)C)cc4c3B(c3cc5c(cc3N4c3ccc4oc6ccccc6c4c3)C(C)(C)CCC5(C)C)c3ccc4oc5c(C(C)(C)C)cccc5c4c32)c(-c2ccccc2)c1]

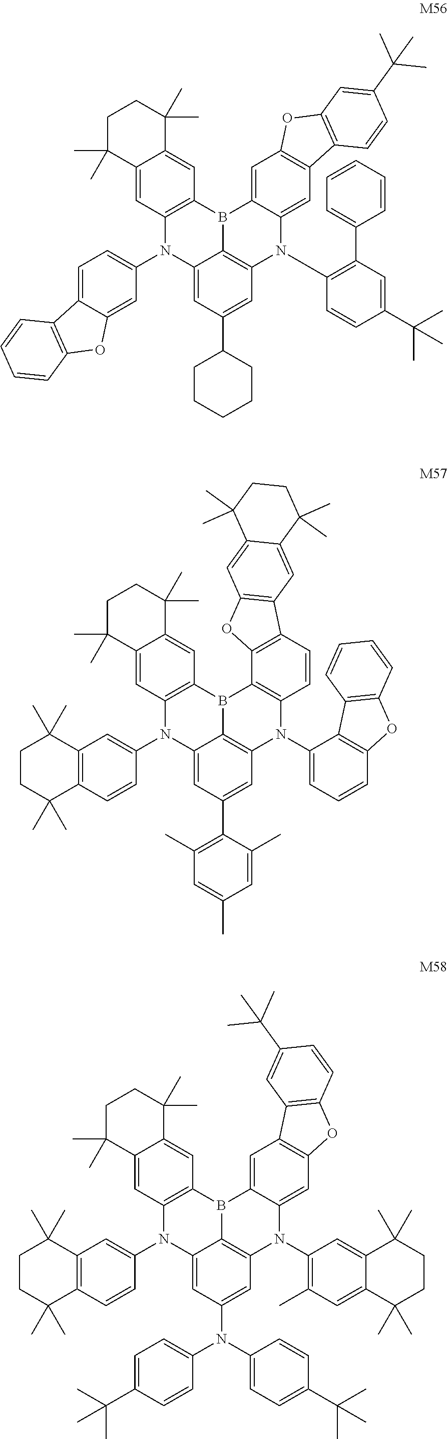 [SMILES: CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)oc2cc(C(C)(C)C)ccc24)c(-c2ccccc2)c1 ; Cc1cc(C)c(-c2cc3c4c(c2)N(c2cccc5oc6ccccc6c25)c2ccc5c(oc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc2c(cc1N1c3cc4oc5ccc(C(C)(C)C)cc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C]

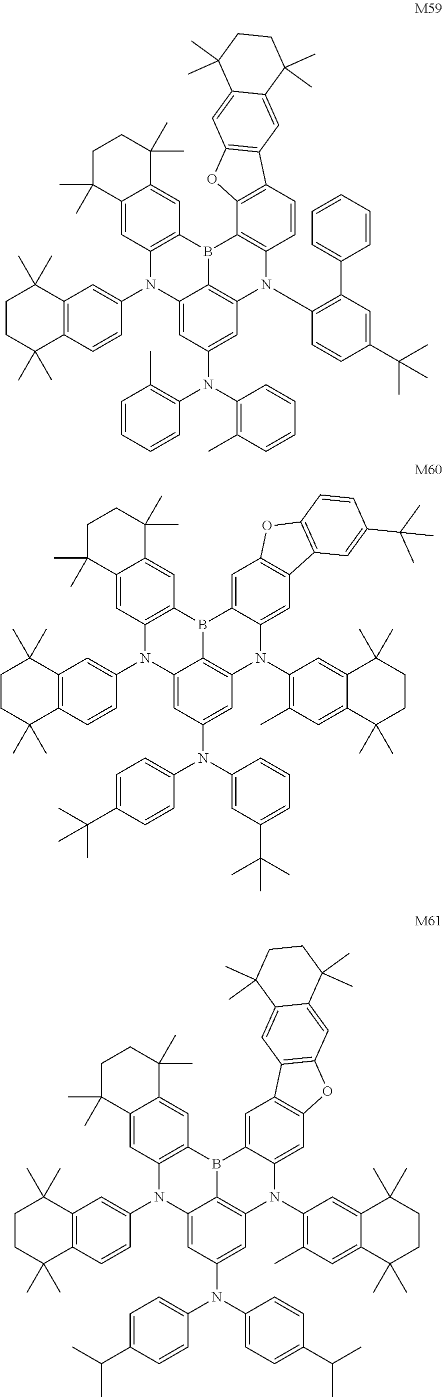

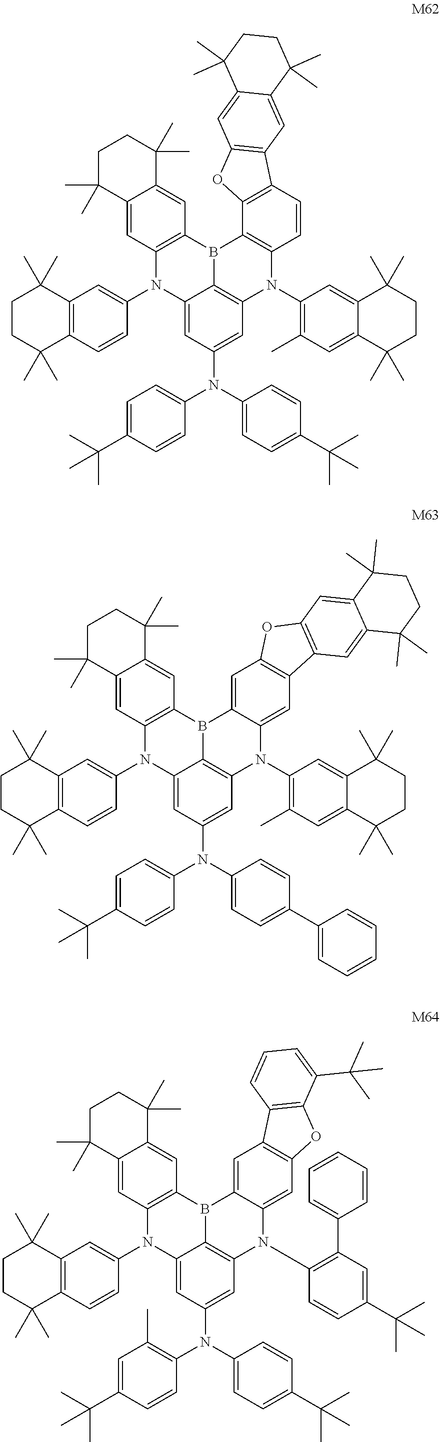

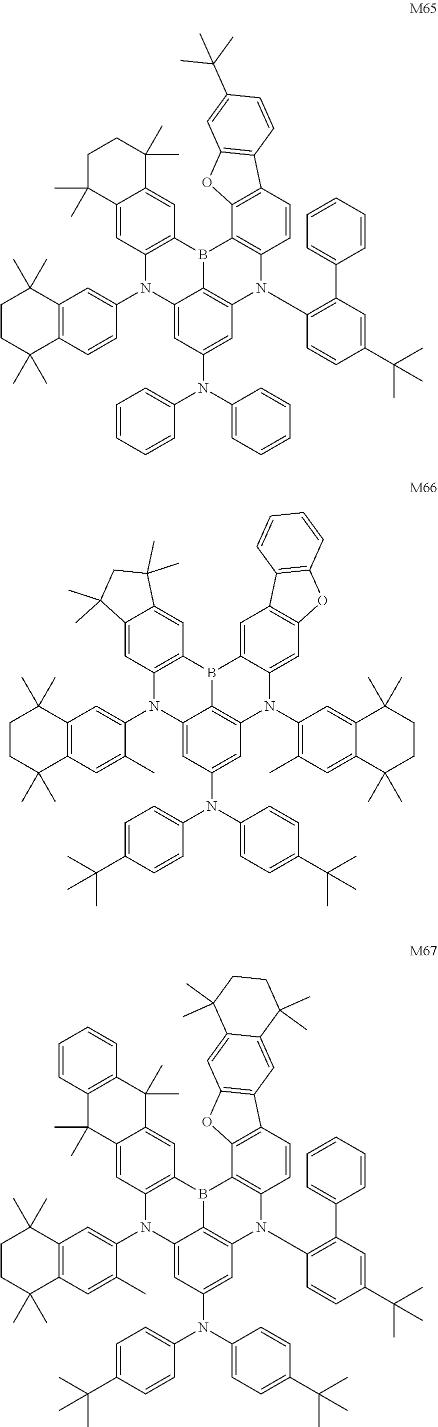 [SMILES: CC(C)(C)c1ccc(N2c3cc(N(c4ccccc4)c4ccccc4)cc4c3B(c3cc5c(cc3N4c3ccc4c(c3)C(C)(C)CCC4(C)C)C(C)(C)CCC5(C)C)c3c2ccc2c3oc3cc(C(C)(C)C)ccc32)c(-c2ccccc2)c1 ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)oc1ccccc16)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccc(C(C)(C)C)cc1-c1ccccc1)c1ccc5c(oc6cc7c(cc65)C(C)(C)CCC7(C)C)c13)C(C)(C)c1ccccc1C4(C)C)C(C)(C)CCC2(C)C]

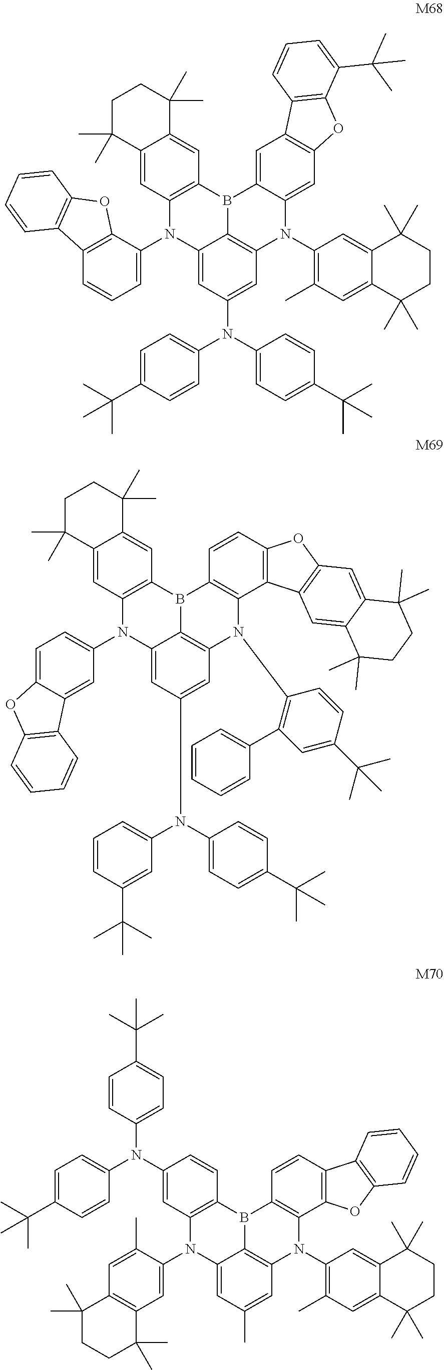

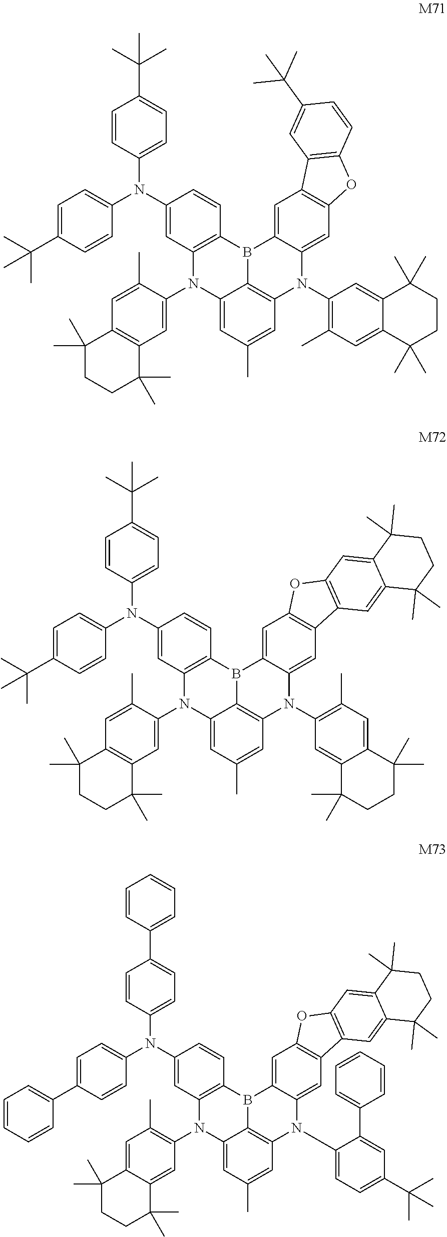 [SMILES: Cc1cc2c3c(c1)N(c1cc4c(cc1C)C(C)(C)CCC4(C)C)c1cc4oc5ccc(C(C)(C)C)cc5c4cc1B3c1ccc(N(c3ccc(C(C)(C)C)cc3)c3ccc(C(C)(C)C)cc3)cc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(N(c3ccc(C(C)(C)C)cc3)c3ccc(C(C)(C)C)cc3)cc1N2c1cc2c(cc1C)C(C)(C)CCC2(C)C)oc1cc2c(cc14)C(C)(C)CCC2(C)C ; Cc1cc2c3c(c1)N(c1ccc(C(C)(C)C)cc1-c1ccccc1)c1cc4c(cc1B3c1ccc(N(c3ccc(-c5ccccc5)cc3)c3ccc(-c5ccccc5)cc3)cc1N2c1cc2c(cc1C)C(C)(C)CCC2(C)C)oc1cc2c(cc14)C(C)(C)CCC2(C)C]

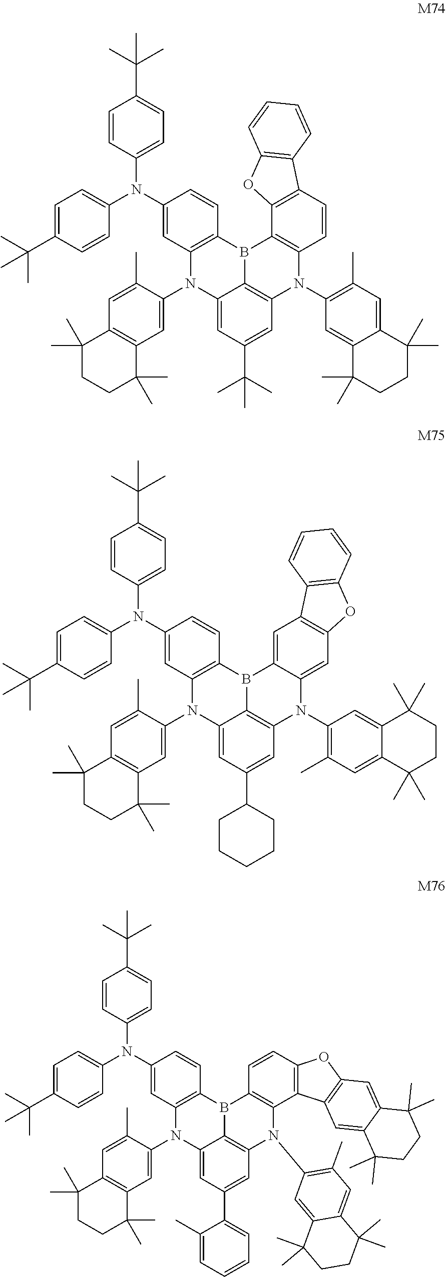

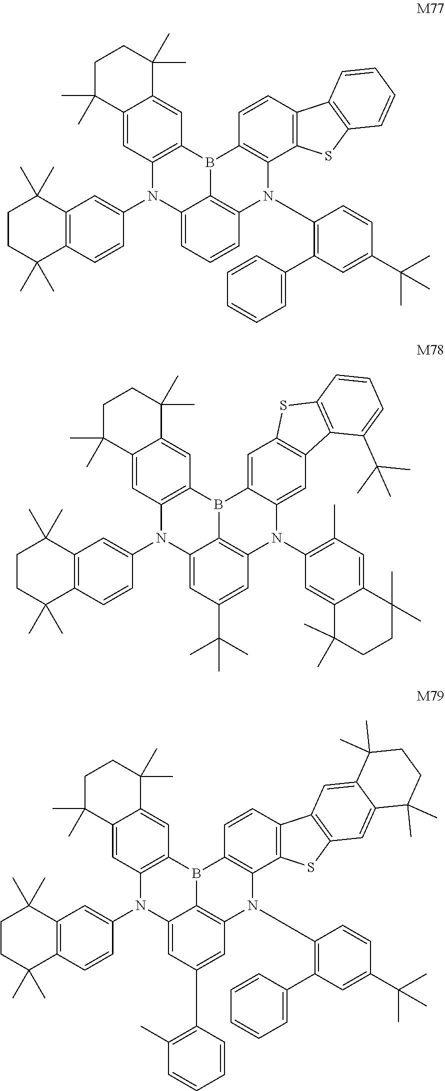 [SMILES: CC(C)(C)c1ccc(N2c3cccc4c3B(c3cc5c(cc3N4c3ccc4c(c3)C(C)(C)CCC4(C)C)C(C)(C)CCC5(C)C)c3ccc4c(sc5ccccc54)c32)c(-c2ccccc2)c1 ; Cc1cc2c(cc1N1c3cc4c(cc3B3c5cc6c(cc5N(c5ccc7c(c5)C(C)(C)CCC7(C)C)c5cc(C(C)(C)C)cc1c53)C(C)(C)CCC6(C)C)sc1cccc(C(C)(C)C)c14)C(C)(C)CCC2(C)C ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C]

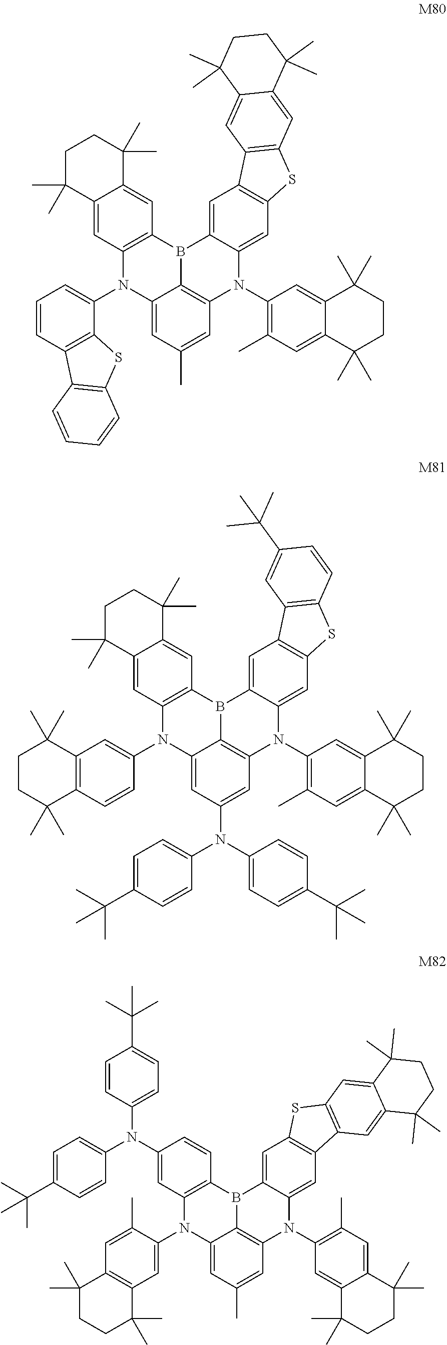 [SMILES: Cc1cc2c3c(c1)N(c1cccc4c1sc1ccccc14)c1cc4c(cc1B3c1cc3c(cc1N2c1cc2c(cc1C)C(C)(C)CCC2(C)C)sc1cc2c(cc13)C(C)(C)CCC2(C)C)C(C)(C)CCC4(C)C ; Cc1cc2c(cc1N1c3cc4sc5ccc(C(C)(C)C)cc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C ; Cc1cc2c3c(c1)N(c1cc4c(cc1C)C(C)(C)CCC4(C)C)c1cc4c(cc1B3c1ccc(N(c3ccc(C(C)(C)C)cc3)c3ccc(C(C)(C)C)cc3)cc1N2c1cc2c(cc1C)C(C)(C)CCC2(C)C)sc1cc2c(cc14)C(C)(C)CCC2(C)C]

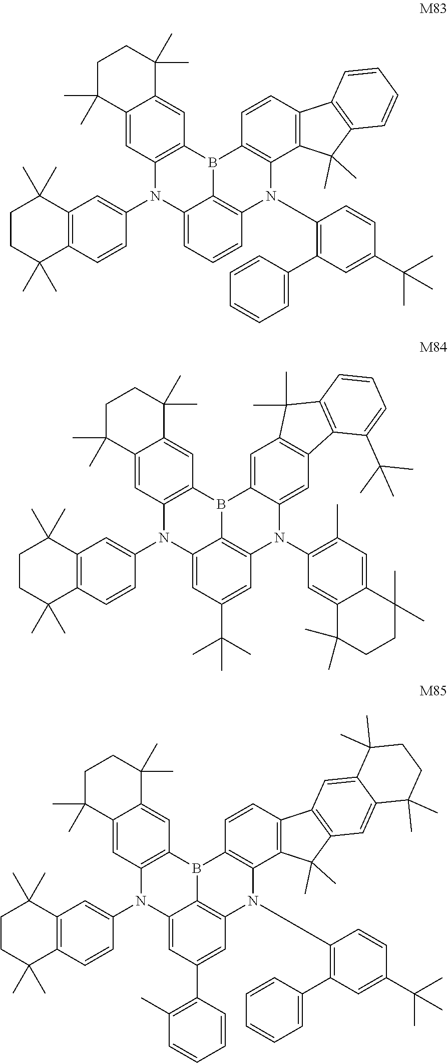 [SMILES: CC(C)(C)c1ccc(N2c3cccc4c3B(c3cc5c(cc3N4c3ccc4c(c3)C(C)(C)CCC4(C)C)C(C)(C)CCC5(C)C)c3ccc4c(c32)C(C)(C)c2ccccc2-4)c(-c2ccccc2)c1 ; Cc1cc2c(cc1N1c3cc4c(cc3B3c5cc6c(cc5N(c5ccc7c(c5)C(C)(C)CCC7(C)C)c5cc(C(C)(C)C)cc1c53)C(C)(C)CCC6(C)C)C(C)(C)c1cccc(C(C)(C)C)c1-4)C(C)(C)CCC2(C)C ; Cc1ccccc1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1ccc2c(c1)C(C)(C)CCC2(C)C)C(C)(C)CCC3(C)C]

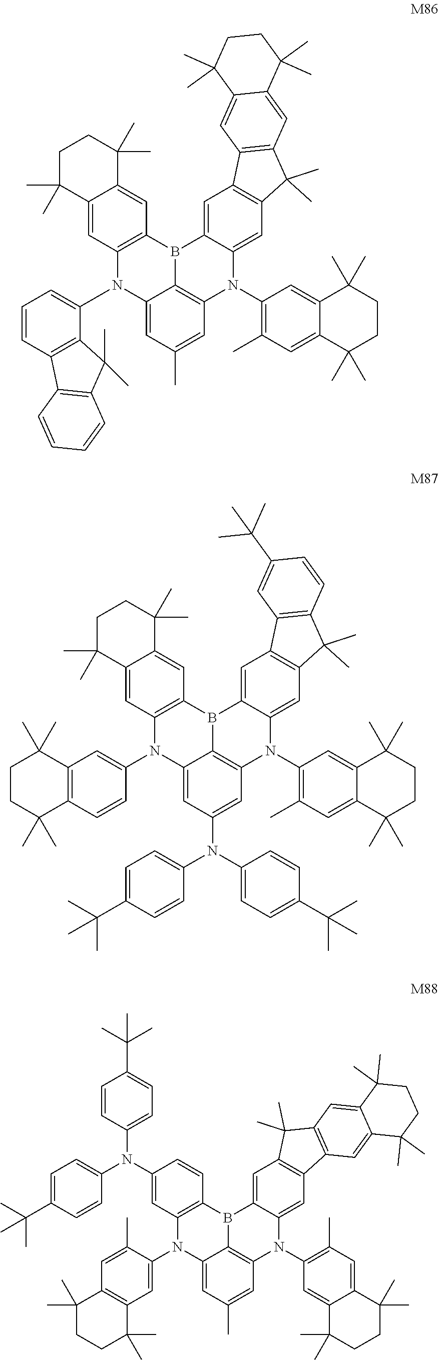 [SMILES: Cc1cc2c3c(c1)N(c1cccc4c1C(C)(C)c1ccccc1-4)c1cc4c(cc1B3c1cc3c(cc1N2c1cc2c(cc1C)C(C)(C)CCC2(C)C)C(C)(C)c1cc2c(cc1-3)C(C)(C)CCC2(C)C)C(C)(C)CCC4(C)C ; Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)-c1cc(C(C)(C)C)ccc1C4(C)C)C(C)(C)CCC2(C)C ; Cc1cc2c3c(c1)N(c1cc4c(cc1C)C(C)(C)CCC4(C)C)c1cc4c(cc1B3c1ccc(N(c3ccc(C(C)(C)C)cc3)c3ccc(C(C)(C)C)cc3)cc1N2c1cc2c(cc1C)C(C)(C)CCC2(C)C)C(C)(C)c1cc2c(cc1-4)C(C)(C)CCC2(C)C]

### Comparative Examples 1-1 to 1-5

Devices were manufactured in the same manner as in Example 1-1 except that compounds described in the following Table 1 were employed as the dopant of the light emitting layer.

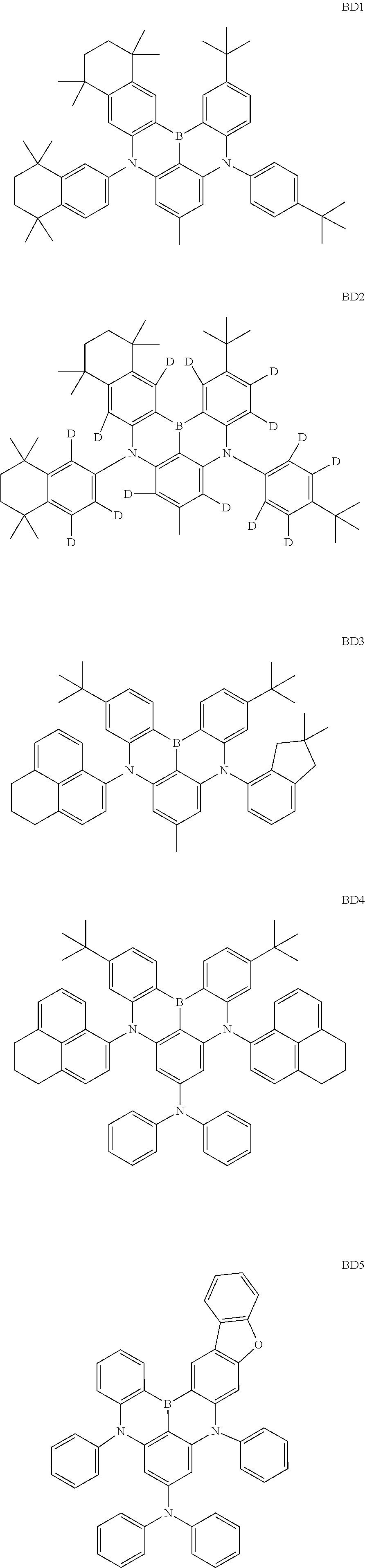

For each of the organic light emitting devices manufactured in the examples and the comparative examples, efficiency, lifetime and color coordinate (based on 1931 CIE color coordinate) at current density of 10 mA/cm² were measured, and the results are shown in the following Table 1.

TABLE 1

| | | | Quantum | |
|---|---|---|---|---|
| | | Voltage | Efficiency | Lifetime |
| | Dopant | (V) | (EQE) | T97 (hr) |
| Example 1-1 | Compound M1 | 3.41 | 9.6 | 300 |
| Example 1-2 | Compound M2 | 3.32 | 10.1 | 302 |
| Example 1-3 | Compound M3 | 3.30 | 10.1 | 302 |
| Example 1-4 | Compound M4 | 3.42 | 10.3 | 295 |
| Example 1-5 | Compound M5 | 3.31 | 9.8 | 297 |
| Example 1-6 | Compound M6 | 3.51 | 9.6 | 300 |
| Example 1-7 | Compound M7 | 3.42 | 10.1 | 303 |
| Example 1-8 | Compound M8 | 3.23 | 10.1 | 302 |
| Example 1-9 | Compound M9 | 3.32 | 10.3 | 303 |
| Example 1-10 | Compound M10 | 3.35 | 10.2 | 303 |
| Example 1-11 | Compound M11 | 3.34 | 9.7 | 300 |
| Example 1-12 | Compound M12 | 3.32 | 10.1 | 303 |
| Example 1-13 | Compound M13 | 3.41 | 10.2 | 302 |
| Example 1-14 | Compound M14 | 3.41 | 10.3 | 298 |
| Example 1-15 | Compound M15 | 3.43 | 10.4 | 302 |
| Example 1-16 | Compound M16 | 3.33 | 10.1 | 298 |
| Example 1-17 | Compound M17 | 3.34 | 9.6 | 399 |
| Example 1-18 | Compound M18 | 3.42 | 10.4 | 296 |
| Example 1-19 | Compound M19 | 3.36 | 10.1 | 298 |
| Example 1-20 | Compound M20 | 3.44 | 10 | 303 |
| Example 1-21 | Compound M21 | 3.33 | 10.2 | 298 |
| Example 1-22 | Compound M22 | 3.22 | 9.6 | 299 |
| Example 1-23 | Compound M23 | 3.40 | 10.2 | 303 |
| Example 1-24 | Compound M24 | 3.31 | 9.9 | 301 |
| Example 1-25 | Compound M25 | 3.33 | 10.4 | 302 |
| Example 1-26 | Compound M26 | 3.44 | 10.4 | 303 |
| Example 1-27 | Compound M27 | 3.35 | 10.6 | 296 |
| Example 1-28 | Compound M28 | 3.32 | 10.2 | 298 |
| Example 1-29 | Compound M29 | 3.40 | 10.3 | 302 |
| Example 1-30 | Compound M30 | 3.33 | 10 | 300 |
| Example 1-31 | Compound M31 | 3.31 | 10 | 302 |
| Example 1-32 | Compound M32 | 3.35 | 10.1 | 303 |
| Example 1-33 | Compound M33 | 3.43 | 10.2 | 295 |
| Example 1-34 | Compound M34 | 3.42 | 10.1 | 299 |
| Example 1-35 | Compound M35 | 3.21 | 10.1 | 303 |
| Example 1-36 | Compound M36 | 3.45 | 9.9 | 299 |
| Example 1-37 | Compound M37 | 3.34 | 10.6 | 296 |
| Example 1-38 | Compound M38 | 3.33 | 10.1 | 298 |
| Example 1-39 | Compound M39 | 3.42 | 9.9 | 301 |
| Example 1-40 | Compound M40 | 3.46 | 10 | 300 |
| Example 1-41 | Compound M41 | 3.42 | 9.9 | 298 |
| Example 1-42 | Compound M42 | 3.44 | 10.5 | 296 |
| Example 1-43 | Compound M43 | 3.33 | 10.2 | 302 |
| Example 1-44 | Compound M44 | 3.31 | 10.2 | 302 |
| Example 1-45 | Compound M45 | 3.30 | 10.4 | 296 |
| Example 1-46 | Compound M46 | 3.44 | 9.9 | 301 |
| Example 1-47 | Compound M47 | 3.33 | 10.5 | 302 |
| Example 1-48 | Compound M48 | 3.30 | 10.4 | 303 |
| Example 1-49 | Compound M49 | 3.42 | 10.6 | 296 |
| Example 1-50 | Compound M50 | 3.33 | 10.2 | 298 |
| Example 1-51 | Compound M51 | 3.44 | 9.7 | 301 |
| Example 1-52 | Compound M52 | 3.51 | 10.5 | 302 |
| Example 1-53 | Compound M53 | 3.20 | 10.5 | 303 |
| Example 1-54 | Compound M54 | 3.32 | 10.4 | 294 |
| Example 1-55 | Compound M55 | 3.33 | 9.8 | 298 |
| Example 1-56 | Compound M56 | 3.37 | 10.3 | 296 |
| Example 1-57 | Compound M57 | 3.21 | 10.5 | 301 |
| Example 1-58 | Compound M58 | 3.44 | 10.7 | 301 |
| Example 1-59 | Compound M59 | 3.32 | 10.7 | 302 |
| Example 1-60 | Compound M60 | 3.34 | 10.8 | 296 |
| Example 1-61 | Compound M61 | 3.36 | 10.8 | 303 |
| Example 1-62 | Compound M62 | 3.34 | 10.8 | 302 |
| Example 1-63 | Compound M63 | 3.32 | 11 | 297 |
| Example 1-64 | Compound M64 | 3.36 | 10.4 | 302 |
| Example 1-65 | Compound M65 | 3.32 | 10.4 | 301 |
| Example 1-66 | Compound M66 | 3.31 | 10.7 | 302 |
| Example 1-67 | Compound M67 | 3.42 | 10.7 | 303 |
| Example 1-68 | Compound M68 | 3.25 | 10.4 | 302 |
| Example 1-69 | Compound M69 | 3.32 | 10.1 | 297 |
| Example 1-70 | Compound M70 | 3.43 | 9.9 | 299 |
| Example 1-71 | Compound M71 | 3.34 | 10.4 | 303 |
| Example 1-72 | Compound M72 | 3.42 | 10.9 | 295 |
| Example 1-73 | Compound M73 | 3.31 | 10.6 | 295 |
| Example 1-74 | Compound M74 | 3.25 | 10.4 | 302 |
| Example 1-75 | Compound M75 | 3.31 | 10.4 | 301 |
| Example 1-76 | Compound M76 | 3.32 | 10.4 | 296 |
| Example 1-77 | Compound M77 | 3.46 | 9.3 | 300 |
| Example 1-78 | Compound M78 | 3.52 | 10.1 | 295 |
| Example 1-79 | Compound M79 | 3.43 | 9.6 | 299 |
| Example 1-80 | Compound M80 | 3.42 | 10.1 | 301 |
| Example 1-81 | Compound M81 | 3.44 | 10.1 | 301 |
| Example 1-82 | Compound M82 | 3.32 | 10.6 | 294 |
| Example 1-83 | Compound M83 | 3.33 | 9.2 | 299 |
| Example 1-84 | Compound M84 | 3.44 | 10 | 294 |
| Example 1-85 | Compound M85 | 3.32 | 9.5 | 299 |
| Example 1-86 | Compound M86 | 3.41 | 10 | 301 |
| Example 1-87 | Compound M87 | 3.34 | 10 | 301 |
| Example 1-88 | Compound M88 | 3.32 | 10.5 | 294 |
| Comparative | BD1 | 3.91 | 7.7 | 203 |
| Example 1-1 | | | | |
| Comparative | BD2 | 3.92 | 7.7 | 220 |
| Example 1-2 | | | | |
| Comparative | BD3 | 3.79 | 7.9 | 210 |
| Example 1-3 | | | | |
| Comparative | BD4 | 3.93 | 7.8 | 212 |
| Example 1-4 | | | | |
| Comparative | BD5 | 3.72 | 8 | 210 |
| Example 1-5 | | | | |

As identified in Table 1, it was seen that the voltage was lowered and efficiency and lifetime of the device were enhanced when using the compound of Chemical Formula 1 of the present disclosure as a dopant of a light emitting layer of the organic light emitting device. Specifically, compared to Comparative Examples 1-1 to 1-4 (BD1 to BD4 having benzene fused to the core) in which a tricyclic ring (dibenzofuran, dibenzothiophene or fluorene) is not fused to the core unlike Chemical Formula 1 of the present disclosure, the devices of Examples 1-1 to 1-88 had increased lifetime and efficiency, and decreased voltage, and compared to Comparative Example 1-5 (BD5) that does not include an aliphatic hydrocarbon ring, the devices of Examples 1-1 to 1-88 had increased lifetime and efficiency, and decreased voltage.

### Example 2-1

A glass substrate on which indium tin oxide (ITO) was coated as a thin film to a thickness of 1,400 Å was placed in distilled water containing dissolved detergent and ultrasonically cleaned. Herein, a product of Fischer Co. was used as the detergent, and as the distilled water, distilled water filtered twice with a filter manufactured by Millipore Co. was used. After the ITO was cleaned for 30 minutes, ultrasonic cleaning was repeated twice using distilled water for 10 minutes. After the cleaning with distilled water was finished, the substrate was ultrasonically cleaned with solvents of isopropyl alcohol, acetone and methanol, then dried, and then transferred to a plasma cleaner. The substrate was cleaned for 5 minutes using oxygen plasma, and then transferred to a vacuum deposition apparatus.

On the transparent ITO electrode prepared as above, the following compounds HI-A and HAT-CN were thermal vacuum deposited to 650 Å and 50 Å, respectively, to form first and second hole injection layers. A hole transfer layer was formed on the hole injection layer by vacuum depositing the following compound HT-A to a thickness of 600 Å. On the hole transfer layer, an electron blocking layer was formed by vacuum depositing the following compound HT-B to a thickness of 50 Å.

Subsequently, a light emitting layer was formed on the electron blocking layer by vacuum depositing Compound M1 of the present disclosure as a blue light emitting dopant in 2 parts by weight with respect to 100 parts by weight of the light emitting layer, and the following compound BH2 as a host to a thickness of 200 Å.

Then, on the light emitting layer, the following Compound ET-A was vacuum deposited to 50 Å as a first electron transfer layer, and subsequently, the following compounds ET-B and LiQ were vacuum deposited in a weight ratio of 1:1 to a thickness of 360 Å to form a second electron transfer layer. An electron injection layer was formed on the second electron transfer layer by vacuum depositing compound LiQ to a thickness of 5 Å. On the electron injection layer, a cathode was formed by depositing aluminum and silver in a weight ratio of 10:1 to a thickness of 220 Å, and then depositing aluminum thereon to a thickness of 1000 Å.

In the above-described process, the deposition rates of the organic materials were maintained at 0.4 Å/sec to 0.9 Å/sec, the deposition rate of the aluminum of the cathode was maintained at 2 Å/sec, and the degree of vacuum during the deposition was maintained at 5×10⁻⁸ torr to 1×10⁻⁷ torr, and as a result, an organic light emitting device was manufactured.

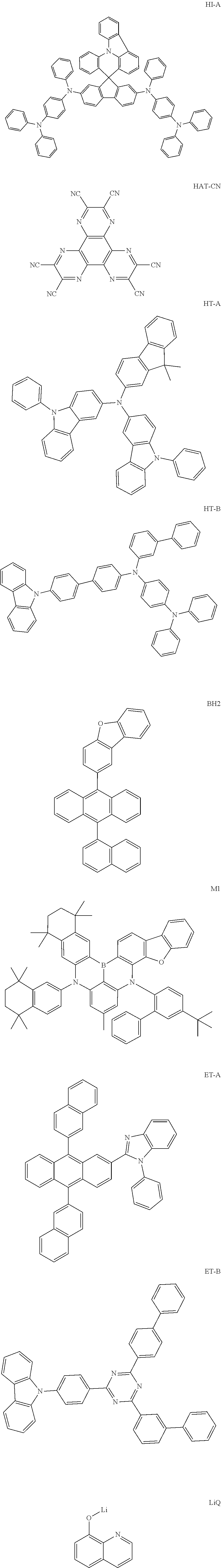

### Examples 2-2 to 2-28

Devices were manufactured in the same manner as in Example 2-1 except that compounds described in the following Table 2 were employed as the dopant of the light emitting layer.

### Comparative Examples 2-1 to 2-5

Devices were manufactured in the same manner as in Example 2-1 except that compounds described in the following Table 2 were employed as the dopant of the light emitting layer.

TABLE 2

| | | | Quantum | |
|---|---|---|---|---|
| | | Voltage | Efficiency | Lifetime |
| | Dopant | (V) | (EQE) | T97 (hr) |
| Example 2-1 | Compound M1 | 3.24 | 10.5 | 255 |
| Example 2-2 | Compound M3 | 3.15 | 10.6 | 257 |
| Example 2-3 | Compound M4 | 3.22 | 10.8 | 251 |
| Example 2-4 | Compound M5 | 3.12 | 10.3 | 252 |
| Example 2-5 | Compound M11 | 3.13 | 10.2 | 255 |
| Example 2-6 | Compound M12 | 3.12 | 10.6 | 258 |
| Example 2-7 | Compound M14 | 3.23 | 10.8 | 253 |
| Example 2-8 | Compound M16 | 3.16 | 10.6 | 253 |
| Example 2-9 | Compound M24 | 3.15 | 10.4 | 256 |
| Example 2-10 | Compound M25 | 3.14 | 10.9 | 257 |
| Example 2-11 | Compound M27 | 3.12 | 11.1 | 252 |
| Example 2-12 | Compound M28 | 3.13 | 10.7 | 253 |
| Example 2-13 | Compound M30 | 3.14 | 10.5 | 255 |
| Example 2-14 | Compound M31 | 3.15 | 10.5 | 257 |
| Example 2-15 | Compound M33 | 3.23 | 10.7 | 251 |
| Example 2-16 | Compound M34 | 3.23 | 10.6 | 254 |
| Example 2-17 | Compound M51 | 3.21 | 10.2 | 256 |
| Example 2-18 | Compound M52 | 3.32 | 11.0 | 257 |
| Example 2-19 | Compound M54 | 3.14 | 10.9 | 250 |
| Example 2-20 | Compound M55 | 3.13 | 10.3 | 253 |
| Example 2-21 | Compound M60 | 3.14 | 11.3 | 252 |
| Example 2-22 | Compound M62 | 3.16 | 11.3 | 257 |
| Example 2-23 | Compound M72 | 3.23 | 11.4 | 251 |
| Example 2-24 | Compound M74 | 3.04 | 10.9 | 257 |
| Example 2-25 | Compound M79 | 3.25 | 10.1 | 254 |
| Example 2-26 | Compound M81 | 3.22 | 10.6 | 256 |
| Example 2-27 | Compound M84 | 3.24 | 10.5 | 250 |
| Example 2-28 | Compound M86 | 3.23 | 10.5 | 256 |
| Comparative | BD1 | 3.71 | 8.1 | 173 |
| Example 2-1 | | | | |
| Comparative | BD2 | 3.70 | 8.1 | 187 |
| Example 2-2 | | | | |
| Comparative | BD3 | 3.62 | 8.3 | 179 |
| Example 2-3 | | | | |
| Comparative | BD4 | 3.73 | 8.2 | 180 |
| Example 2-4 | | | | |
| Comparative | BD5 | 3.54 | 8.4 | 179 |
| Example 2-5 | | | | |

As identified in Table 2, it was seen that the voltage was lowered and efficiency and lifetime of the device were enhanced when using the compound of Chemical Formula 1 of the present disclosure as a dopant of a light emitting layer of the organic light emitting device. Specifically, Specifically, compared to Comparative Examples 2-1 to 2-4 (BD1 to BD4 having benzene fused to the core) in which a tricyclic ring (dibenzofuran, dibenzothiophene or fluorene) is not fused to the core unlike Chemical Formula 1 of the present disclosure, the devices of Examples 2-1 to 2-28 had increased lifetime and efficiency, and decreased voltage, and compared to Comparative Example 2-5 (BD5) that does not include an aliphatic hydrocarbon ring, the devices of Examples 2-1 to 2-had increased lifetime and efficiency, and decreased voltage.

### Example 3-1

A glass substrate on which indium tin oxide (ITO) was coated as a thin film to a thickness of 1,400 Å was placed in distilled water containing dissolved detergent and ultrasonically cleaned. Herein, a product of Fischer Co. was used as the detergent, and as the distilled water, distilled water filtered twice with a filter manufactured by Millipore Co. was used. After the ITO was cleaned for 30 minutes, ultrasonic cleaning was repeated twice using distilled water for 10 minutes. After the cleaning with distilled water was finished, the substrate was ultrasonically cleaned with solvents of isopropyl alcohol, acetone and methanol, then dried, and then transferred to a plasma cleaner. The substrate was cleaned for 5 minutes using oxygen plasma, and then transferred to a vacuum deposition apparatus.

On the transparent ITO electrode prepared as above, the following compounds HI-A and HAT-CN were thermal vacuum deposited to 650 Å and 50 Å, respectively, to form first and second hole injection layers. A hole transfer layer was formed on the hole injection layer by vacuum depositing the following compound HT-A to a thickness of 600 Å. On the hole transfer layer, an electron blocking layer was formed by vacuum depositing the following compound HT-B to a thickness of 50 Å.

Subsequently, a light emitting layer was formed on the electron blocking layer by vacuum depositing Compound M1 of the present disclosure as a blue light emitting dopant in 2 parts by weight with respect to 100 parts by weight of the light emitting layer, and the following BH3 as a host to a thickness of 200 Å.

Then, on the light emitting layer, the following Compound ET-A was vacuum deposited to 50 Å as a first electron transfer layer, and subsequently, the following compounds ET-B and LiQ were vacuum deposited in a weight ratio of 1:1 to a thickness of 360 Å to form a second electron transfer layer. An electron injection layer was formed on the second electron transfer layer by vacuum depositing compound LiQ to a thickness of 5 Å. On the electron injection layer, a cathode was formed by depositing aluminum and silver in a weight ratio of 10:1 to a thickness of 220 Å, and then depositing aluminum thereon to a thickness of 1000 Å.

In the above-described process, the deposition rates of the organic materials were maintained at 0.4 Å/sec to 0.9 Å/sec, the deposition rate of the aluminum of the cathode was maintained at 2 Å/sec, and the degree of vacuum during the deposition was maintained at 5×10⁻⁸ torr to 1×10⁻⁷ torr, and as a result, an organic light emitting device was manufactured.

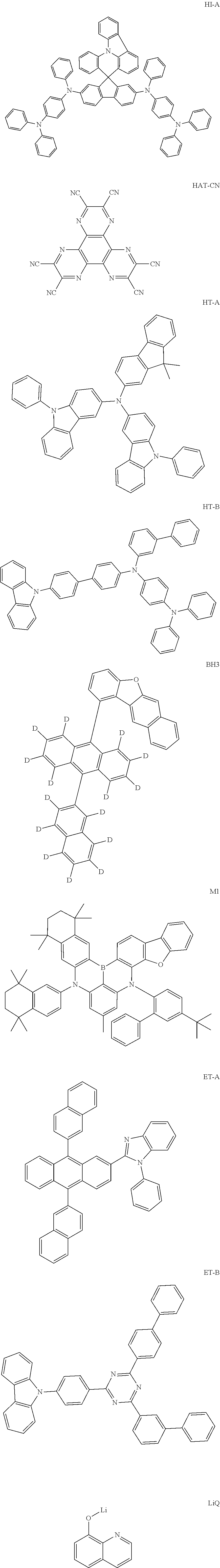

### Examples 3-2 to 3-16

Devices were manufactured in the same manner as in Example 3-1 except that compounds described in the following Table 3 were employed as the dopant of the light emitting layer.

### Comparative Examples 3-1 to 3-5

Devices were manufactured in the same manner as in Example 3-1 except that compounds described in the following Table 3 were employed as the dopant of the light emitting layer.

TABLE 3

| | | | Quantum | |
|---|---|---|---|---|
| | | Voltage | Efficiency | Lifetime |
| | Dopant | (V) | (EQE) | T97 (hr) |
| Example 3-1 | Compound M1 | 3.08 | 9.1 | 450 |
| Example 3-2 | Compound M3 | 3.04 | 9.6 | 453 |
| Example 3-3 | Compound M4 | 3.05 | 9.8 | 443 |
| Example 3-4 | Compound M5 | 3.01 | 9.3 | 446 |
| Example 3-5 | Compound M24 | 3.02 | 9.4 | 452 |
| Example 3-6 | Compound M25 | 3.03 | 9.9 | 453 |
| Example 3-7 | Compound M27 | 3.01 | 10.1 | 444 |
| Example 3-8 | Compound M28 | 3.05 | 9.7 | 447 |
| Example 3-9 | Compound M51 | 3.04 | 9.2 | 452 |
| Example 3-10 | Compound M52 | 3.11 | 10.0 | 453 |
| Example 3-11 | Compound M54 | 3.06 | 9.9 | 441 |
| Example 3-12 | Compound M55 | 3.04 | 9.3 | 447 |
| Example 3-13 | Compound M79 | 3.09 | 9.1 | 449 |
| Example 3-14 | Compound M81 | 3.05 | 9.6 | 452 |
| Example 3-15 | Compound M84 | 3.07 | 9.5 | 441 |
| Example 3-16 | Compound M86 | 3.08 | 9.5 | 452 |
| Comparative | BD1 | 3.51 | 7.3 | 305 |
| Example 3-1 | | | | |
| Comparative | BD2 | 3.52 | 7.3 | 330 |
| Example 3-2 | | | | |
| Comparative | BD3 | 3.42 | 7.5 | 315 |
| Example 3-3 | | | | |
| Comparative | BD4 | 3.56 | 7.4 | 318 |
| Example 3-4 | | | | |
| Comparative | BD5 | 3.33 | 7.6 | 315 |
| Example 3-5 | | | | |

As identified in Table 3, it was seen that the voltage was lowered and efficiency and lifetime of the device were enhanced when using the compound of Chemical Formula 1 of the present disclosure as a dopant of a light emitting layer of the organic light emitting device. Specifically, Specifically, Specifically, compared to Comparative Examples 3-1 to 3-4 (BD1 to BD4 having benzene fused to the core) in which a tricyclic ring (dibenzofuran, dibenzothiophene or fluorene) is not fused to the core unlike Chemical Formula 1 of the present disclosure, the devices of Examples 3-1 to 3-had increased lifetime and efficiency, and decreased voltage, and compared to Comparative Example 3-5 (BD5) that does not include an aliphatic hydrocarbon ring, the devices of Examples 3-1 to 3-16 had increased lifetime and efficiency, and decreased voltage.

As identified in Tables 1 to 3, the materials including an aliphatic hydrocarbon ring and a tricyclic ring (dibenzofuran, dibenzothiophene or fluorene) in the core suppressed intermolecular quenching by the aliphatic hydrocarbon ring, and the efficiency was maximized by increasing an extinction coefficient due to an expansion of conjugation. In addition, produced excitons were rapidly transferred to light emission (increase in efficiency) suppressing stress on the material applied by the remaining excitons, and the lifetime rapidly increased as well since the applied voltage was also lowered.

1. A polycyclic compound of Chemical Formula 1: 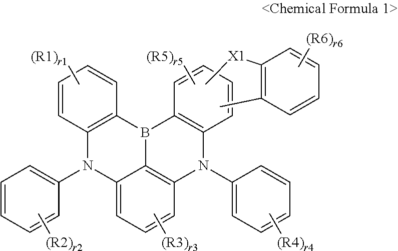
wherein in Chemical Formula 11;
X1 is O, S, or CR7R8;
R1 to R8 are the same as or different from each other, and each independently is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring;
one or more of R1 to R6 bond to adjacent substituents to form a substituted or unsubstituted aliphatic hydrocarbon ring;
r1 and r6 are an integer of 0 to 4, r3 is an integer of 0 to 3, r2 and r4 are an integer of 0 to 5, and r5 is an integer of 0 to 2;
r1+r2+r3+r4+r5+r6 is 2 or greater; and
when r1 to r4 and r6 are each 2 or greater or r5 is 2, the substituents in the parentheses are the same as or different from each other.

2. The polycyclic compound of claim 1, wherein Chemical Formula 1 is any one of the following Chemical Formulae 2 to 6: 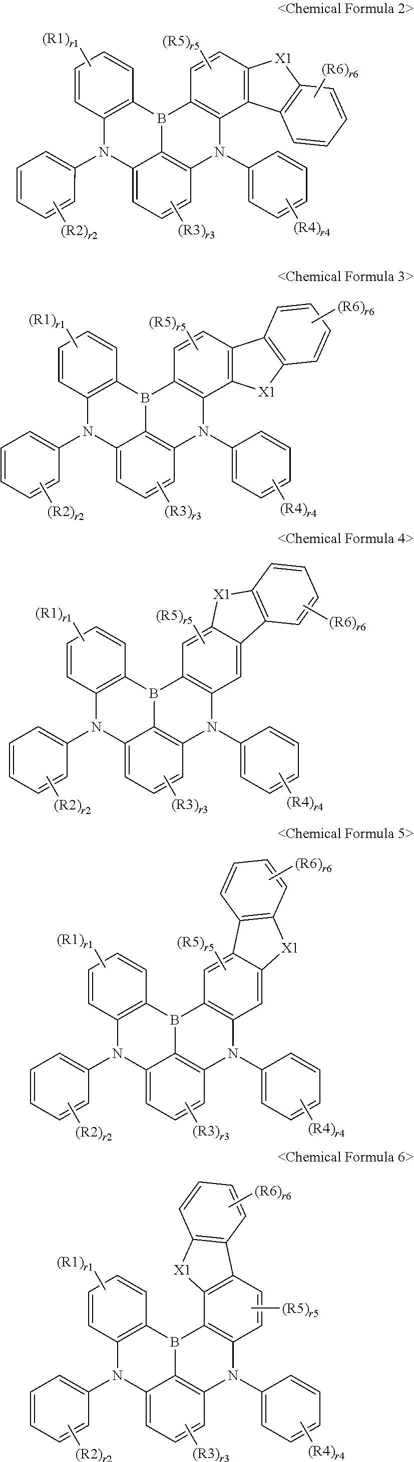
wherein in Chemical Formulae 2 to 6:
X1, R1 to R6 and r1 to r6 have the same definitions as in Chemical Formula 1.

3. The polycyclic compound of claim 1, wherein the substituted or unsubstituted aliphatic hydrocarbon ring formed by one or more of R1 to R6 bonding to adjacent substituents is the following Chemical Formula Cy1: 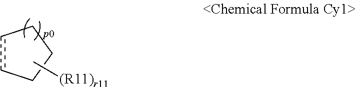
wherein in Chemical Formula Cy1;
a double dotted line is a position fused to Chemical Formula 1;
p0 is 1 or 2;
R11 is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group a substituted or unsubstituted aryloxy group, a substituted or unsubstituted arylthio group, a substituted or unsubstituted heterocyclic group, or a substituted or unsubstituted amine group, or bonds to adjacent substituents to form a substituted or unsubstituted ring; and
r11 is an integer of 0 to 8, and when r11 is 2 or greater, the R11s are the same as or different from each other.

4. The polycyclic compound of claim 1, wherein Chemical Formula 1 is any one of the following Chemical Formulae 101 to 104: 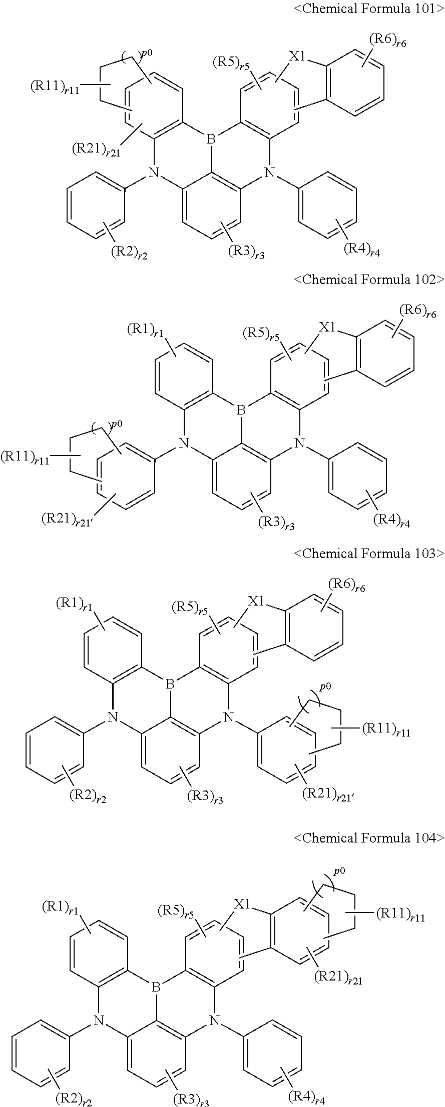
wherein in Chemical Formulae 101 to 104;
X1, R1 to R6 and r1 to r6 have the same definitions as in Chemical Formula 1;
p0 is 1 or 2;
R11 is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group a substituted or unsubstituted silyl group, a substituted or unsubstituted aryl group a substituted or unsubstituted aryloxy group, a substituted or unsubstituted arylthio group, a substituted or unsubstituted heterocyclic group, or a substituted or unsubstituted amine group, or bonds to adjacent substituents to form a substituted or unsubstituted ring;
R21 is hydrogen, deuterium, a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group a substituted or unsubstituted heterocyclic group, or a substituted or unsubstituted amine group;
r11 is an integer of 0 to 8, r21 is an integer of 0 to 2, and r21′ is an integer of 0 to 3; and
when r11 and r21′ are each 2 or greater or r21 is 2, the substituents in the parentheses are the same as or different from each other.

5. The polycyclic compound of claim 1, wherein Chemical Formula 1 is any one of the following Chemical Formulae 201 to 215: 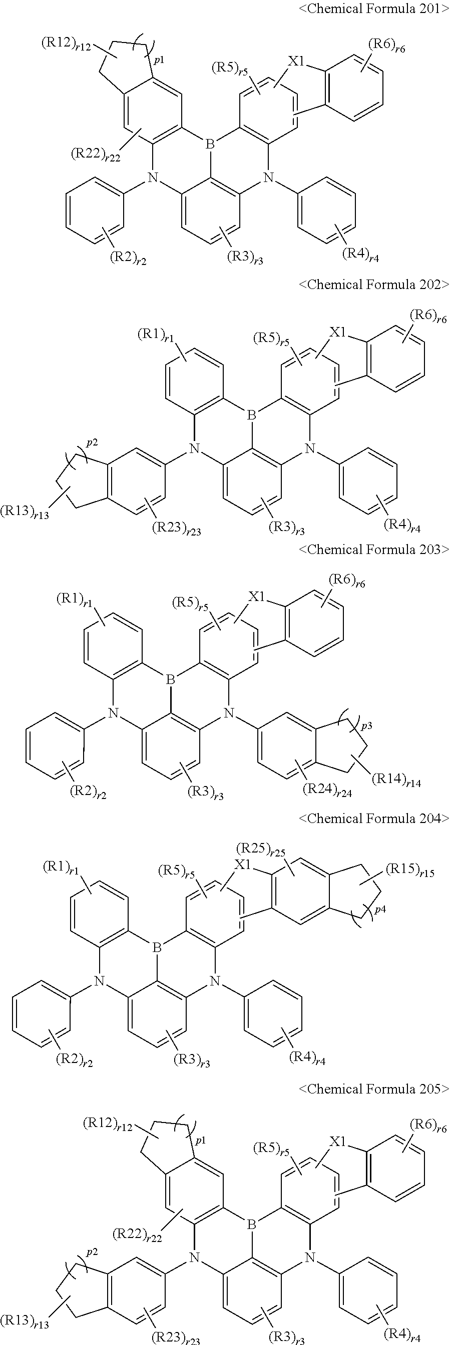 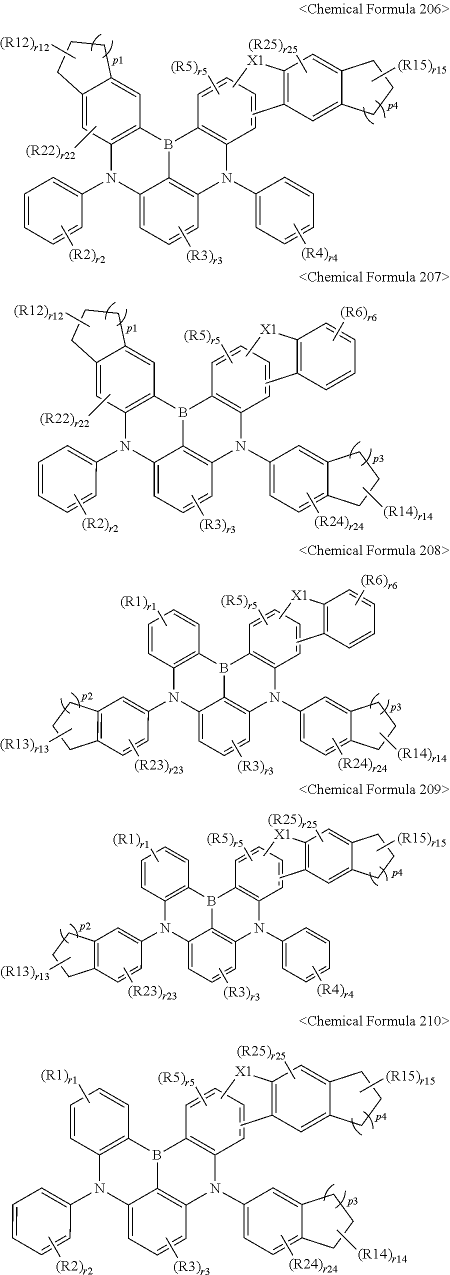 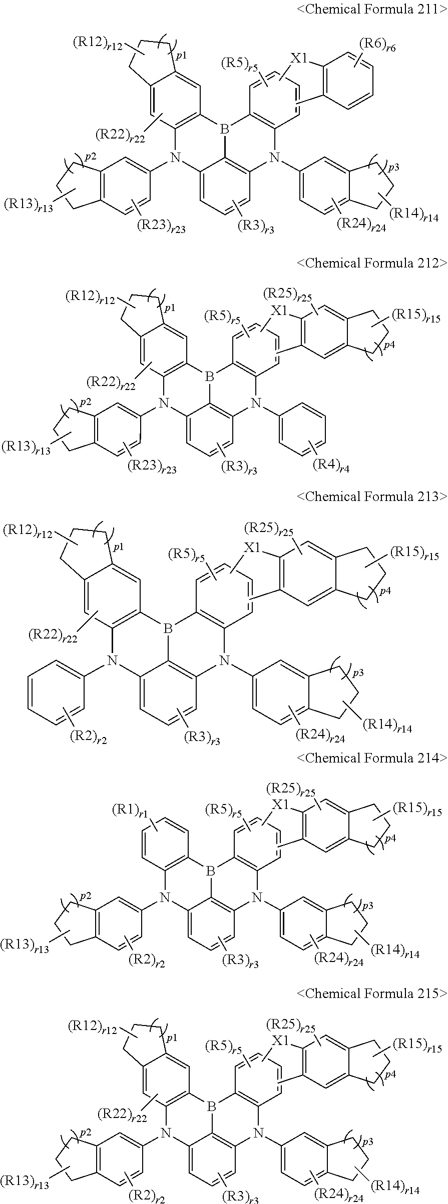
wherein in Chemical Formulae 201 to 215;
X1 and r1 to r6 have the same definitions as in Chemical Formula 1;
p1 to p4 are each 1 or 2;
R1 to R6 and R22 to R25 are the same as or different from each other, and each independently is hydrogen, deuterium a cyano group, a halogen group, a substituted or unsubstituted alkyl group, a substituted or unsubstituted alkoxy group, a substituted or unsubstituted alkylthio group, a substituted or unsubstituted cycloalkyl group a substituted or unsubstituted silyl group, a substituted or unsubstituted aryl group a substituted or unsubstituted aryloxy group, a substituted or unsubstituted arylthio group, a substituted or unsubstituted heterocyclic group, or a substituted or unsubstituted amine group;
R12 to R15 are the same as or different from each other, and each independently is hydrogen, deuterium a cyano group, a halogen group, a substituted or unsubstituted alkyl group, a substituted or unsubstituted alkoxy group, a substituted or unsubstituted alkylthio group, a substituted or unsubstituted cycloalkyl group, a substituted or unsubstituted silyl group, a substituted or unsubstituted aryl group, a substituted or unsubstituted aryloxy group, a substituted or unsubstituted arylthio group, a substituted or unsubstituted heterocyclic group, or a substituted or unsubstituted amine group, or bond to adjacent substituents to form a substituted or unsubstituted ring;
r12 to r15 are each an integer of 0 to 8, r22 and r25 are each an integer of 0 to 2, and r23 and r24 are each an integer of 0 to 3; and
when r12 to r15, r23 and r24 are each 2 or greater or r22 and r25 are 2, the substituents in the parentheses are the same as or different from each other.

6. The polycyclic compound claim 1, wherein R1 to R6 are the same as or different from each other, and each independently is hydrogen; deuterium; an alkyl group that is unsubstituted or substituted with deuterium; a cycloalkyl group; an aryl group that is unsubstituted or substituted with one or more substituents selected from the group consisting of deuterium and an alkyl group, or a substituent linking two or more groups selected from the above-described group; or an amine group that is unsubstituted or substituted with one or more substituents selected from the group consisting of deuterium, an alkyl group, an aryl group, a fused ring group of aromatic hydrocarbon ring and aliphatic hydrocarbon ring, and a heterocyclic group, or a substituent linking two or more groups selected from the above-described group, or bond to adjacent substituents to form a hydrocarbon ring or heteroring that is unsubstituted or substituted with one or more substituents selected from the group consisting of deuterium and an alkyl group, or a substituent linking two or more groups selected from the above-described group; and
the number of carbon atoms of the alkyl group is from 1 to 10, the number of carbon atoms of the cycloalkyl group and the aliphatic hydrocarbon ring is from 3 to 30, the number of carbon atoms of the aryl group and the aromatic hydrocarbon ring is from 6 to 30, the number of carbon atoms of the heteroring is from 2 to 30, and the heteroring includes one or more of N, O, S and Si as a heteroatom.

7. The polycyclic compound of claim 1, wherein the compound of Chemical Formula 1 is one compound selected from among the following compounds:

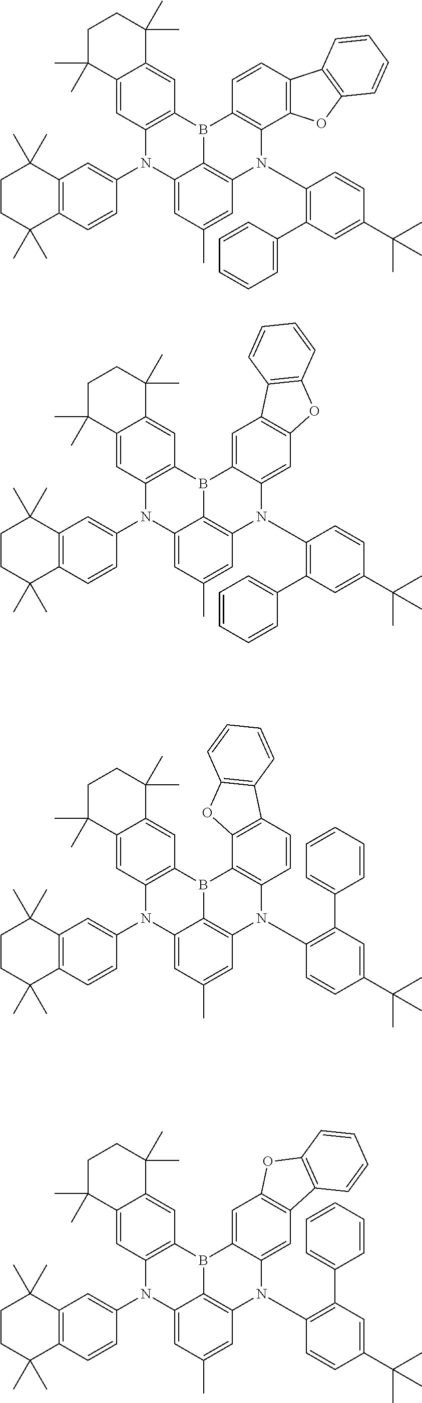

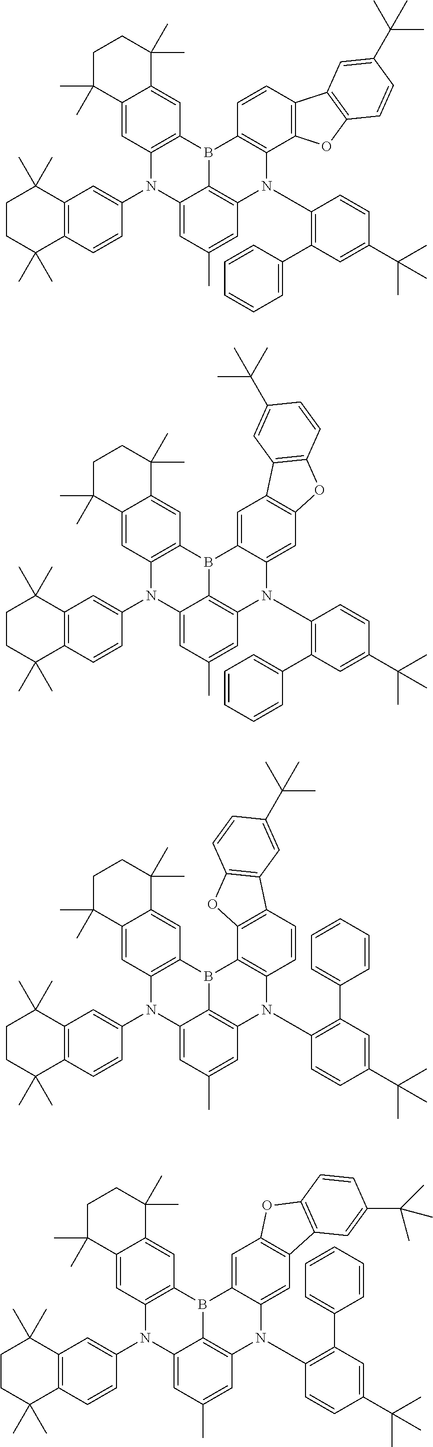

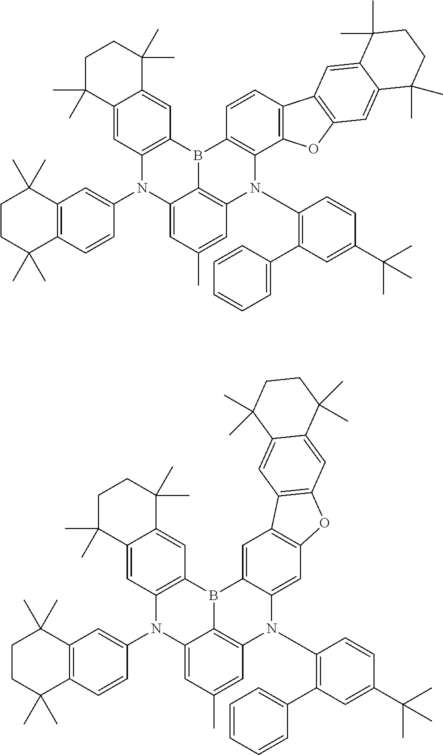 [SMILES: Cc1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C]

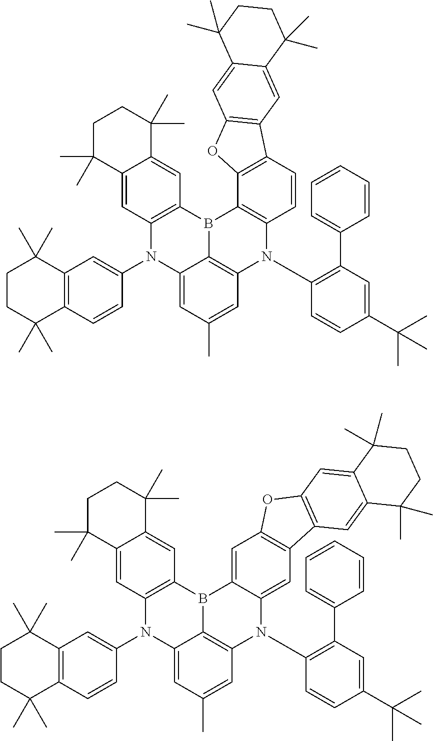 [SMILES: Cc1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1cc2c(cc14)C(C)(C)CCC2(C)C]

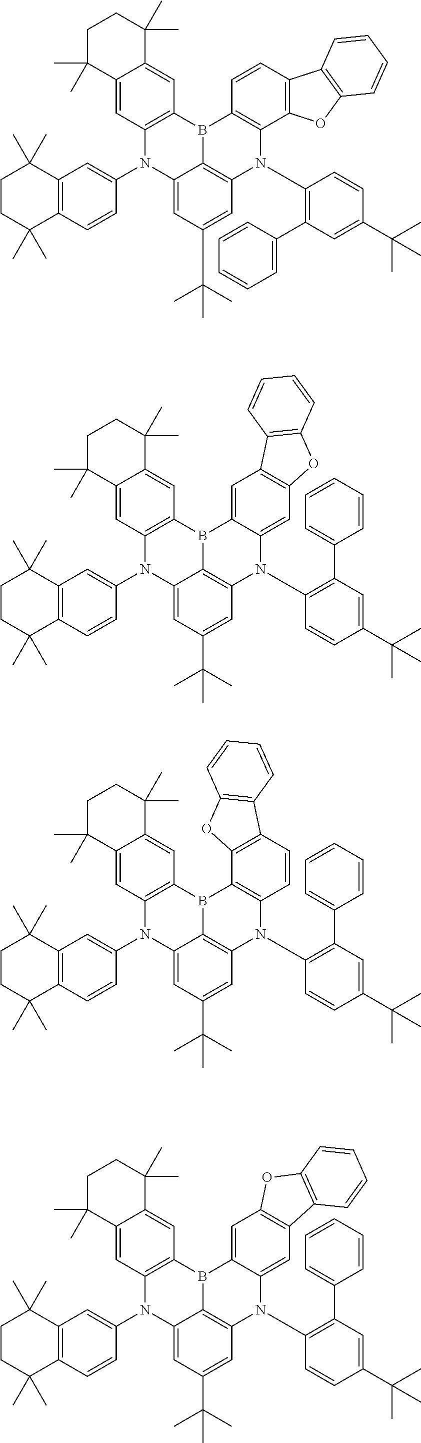

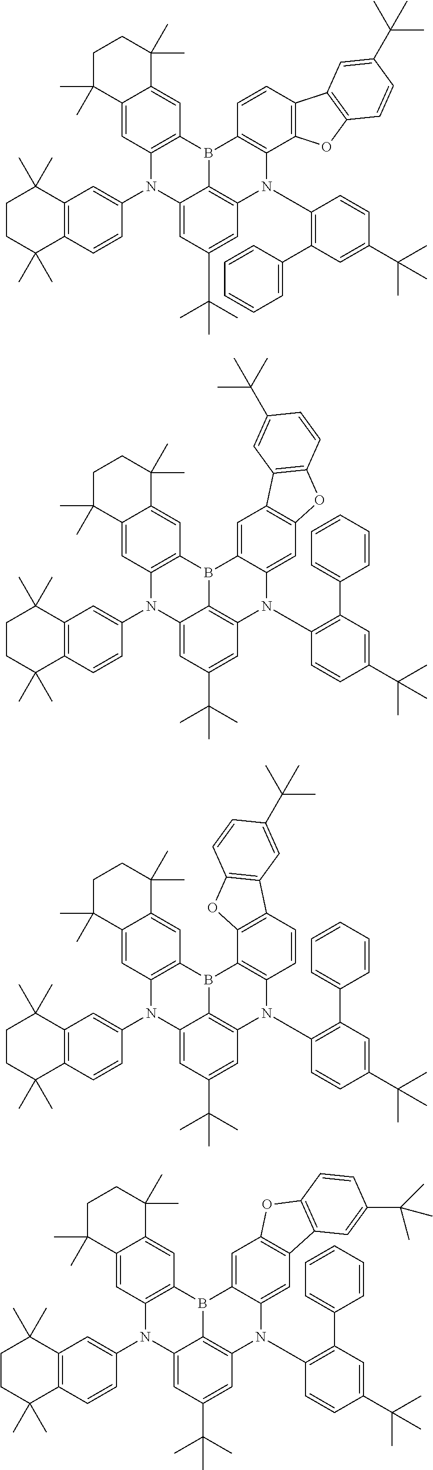

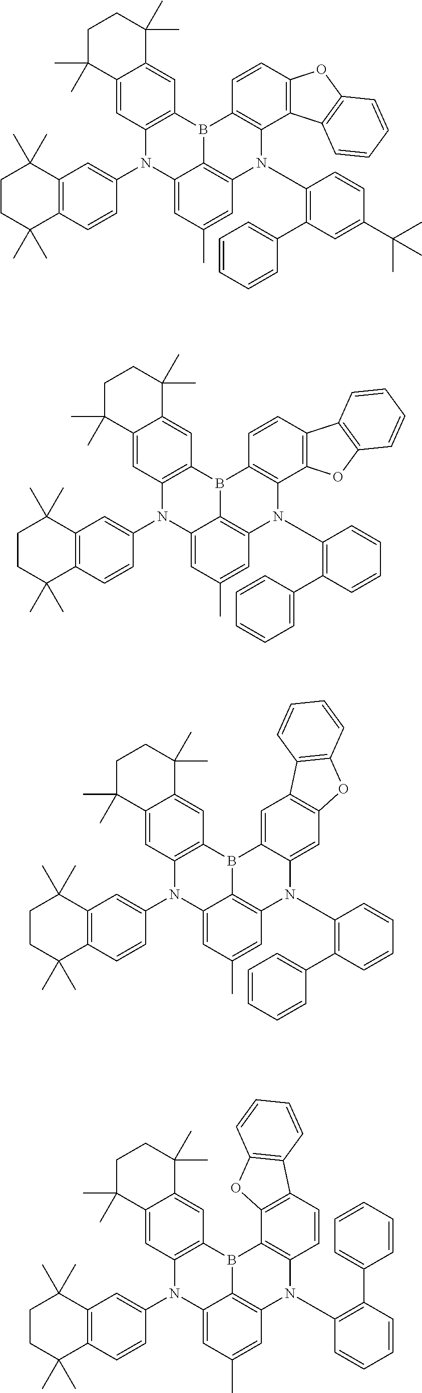 [SMILES: Cc1cc2c3c(c1)N(c1ccc(C(C)(C)C)cc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1cc2c3c(c1)N(c1ccccc1-c1ccccc1)c1c(ccc4c1oc1ccccc14)B3c1cc3c(cc1N2c1ccc2c(c1)C(C)(C)CCC2(C)C)C(C)(C)CCC3(C)C ; Cc1cc2c3c(c1)N(c1ccccc1-c1ccccc1)c1cc4oc5ccccc5c4cc1B3c1cc3c(cc1N2c1ccc2c(c1)C(C)(C)CCC2(C)C)C(C)(C)CCC3(C)C ; Cc1cc2c3c(c1)N(c1ccccc1-c1ccccc1)c1ccc4c(oc5ccccc54)c1B3c1cc3c(cc1N2c1ccc2c(c1)C(C)(C)CCC2(C)C)C(C)(C)CCC3(C)C]

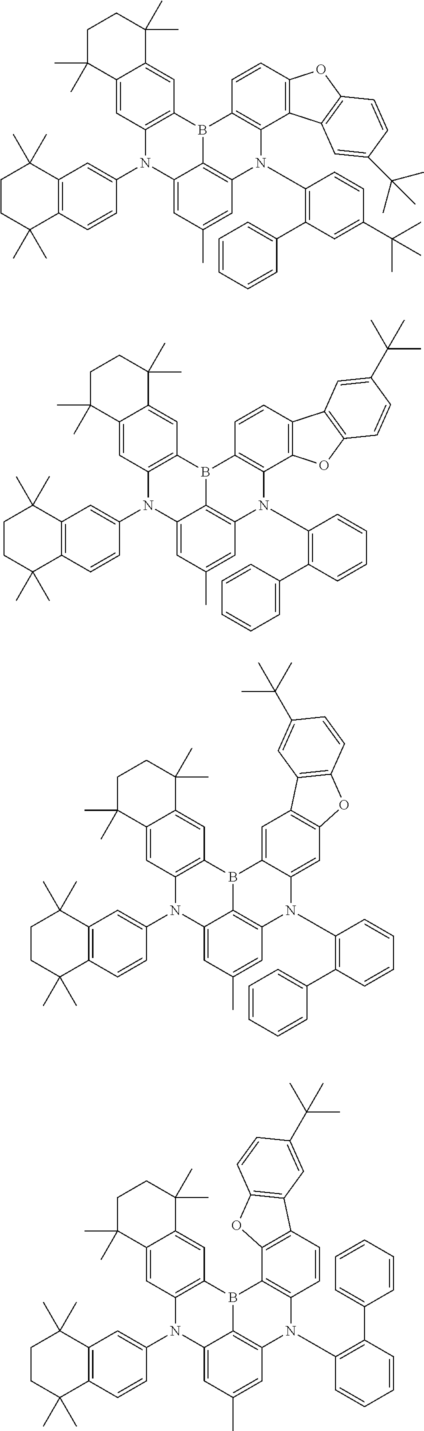

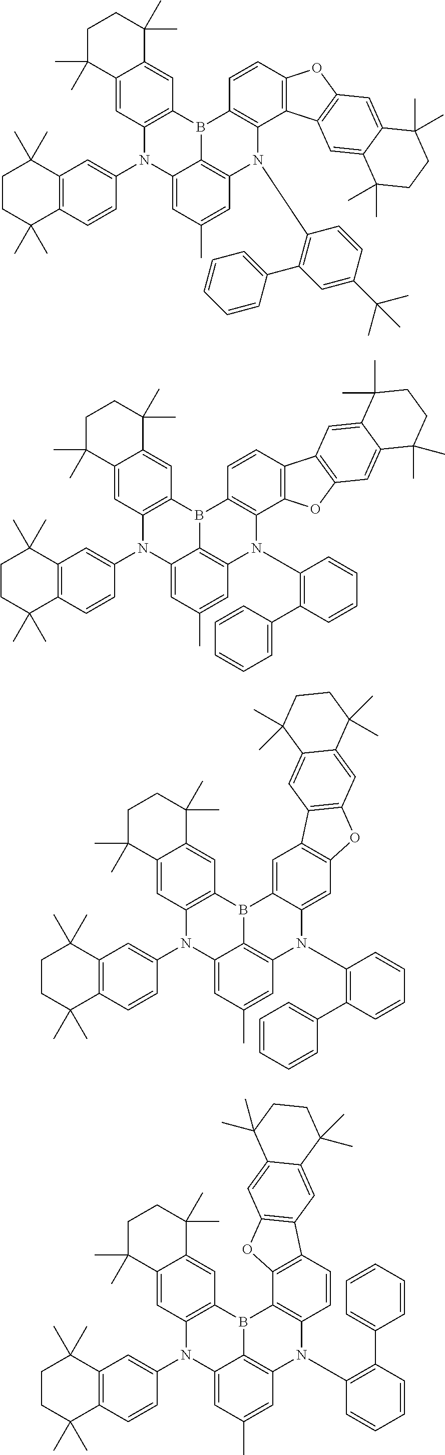

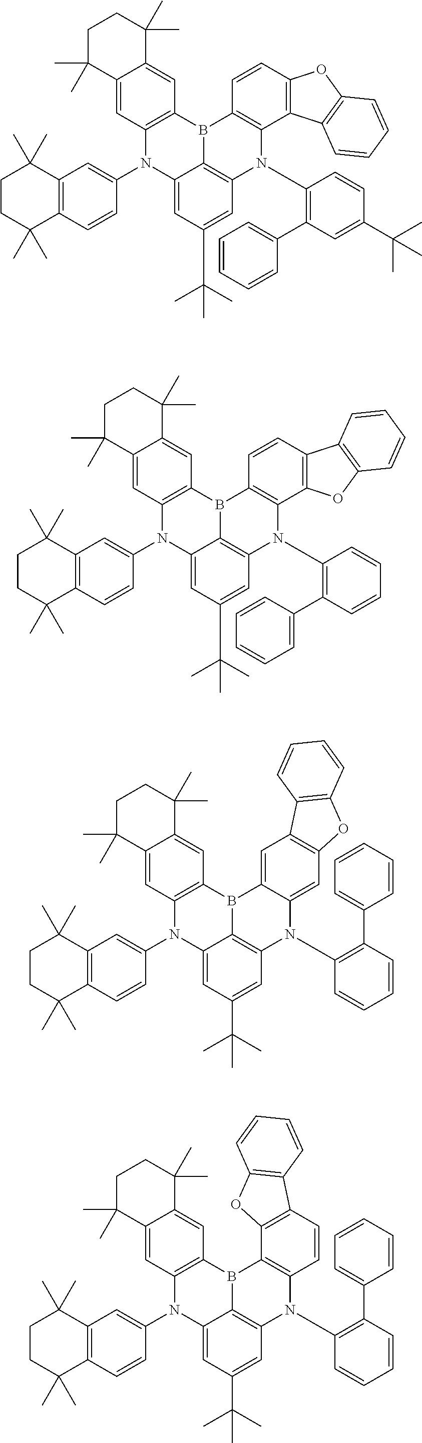 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3ccc4oc5ccccc5c4c32)c(-c2ccccc2)c1 ; CC(C)(C)c1cc2c3c(c1)N(c1ccccc1-c1ccccc1)c1c(ccc4c1oc1ccccc14)B3c1cc3c(cc1N2c1ccc2c(c1)C(C)(C)CCC2(C)C)C(C)(C)CCC3(C)C ; CC(C)(C)c1cc2c3c(c1)N(c1ccccc1-c1ccccc1)c1cc4oc5ccccc5c4cc1B3c1cc3c(cc1N2c1ccc2c(c1)C(C)(C)CCC2(C)C)C(C)(C)CCC3(C)C ; CC(C)(C)c1cc2c3c(c1)N(c1ccccc1-c1ccccc1)c1ccc4c(oc5ccccc54)c1B3c1cc3c(cc1N2c1ccc2c(c1)C(C)(C)CCC2(C)C)C(C)(C)CCC3(C)C]

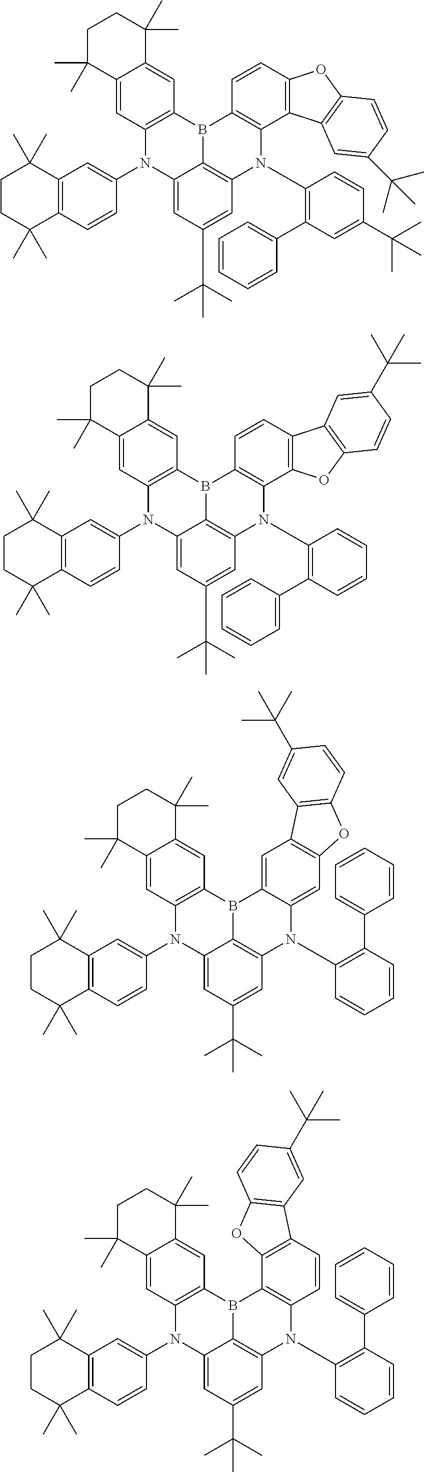

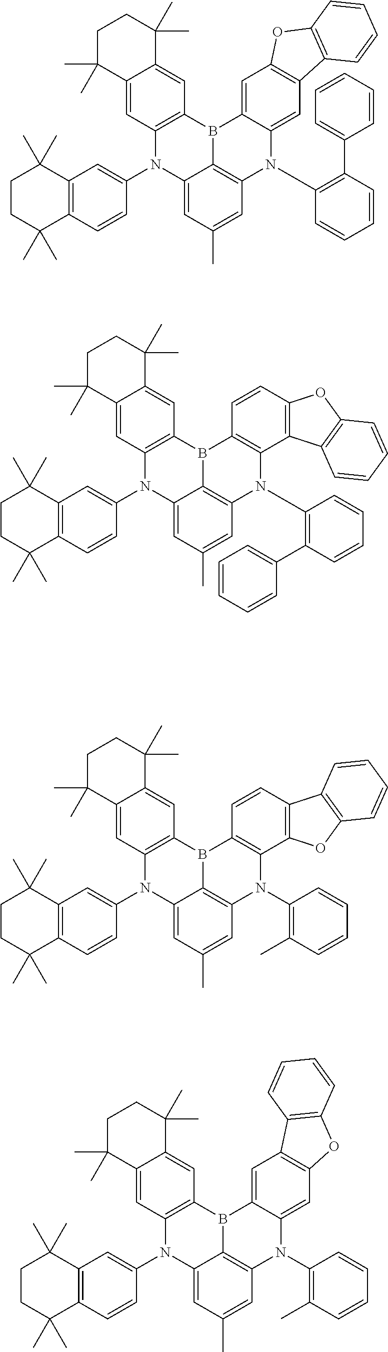 [SMILES: Cc1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccccc14 ; Cc1cc2c3c(c1)N(c1ccccc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1cc2c3c(c1)N(c1ccccc1C)c1c(ccc4c1oc1ccccc14)B3c1cc3c(cc1N2c1ccc2c(c1)C(C)(C)CCC2(C)C)C(C)(C)CCC3(C)C ; Cc1cc2c3c(c1)N(c1ccccc1C)c1cc4oc5ccccc5c4cc1B3c1cc3c(cc1N2c1ccc2c(c1)C(C)(C)CCC2(C)C)C(C)(C)CCC3(C)C]

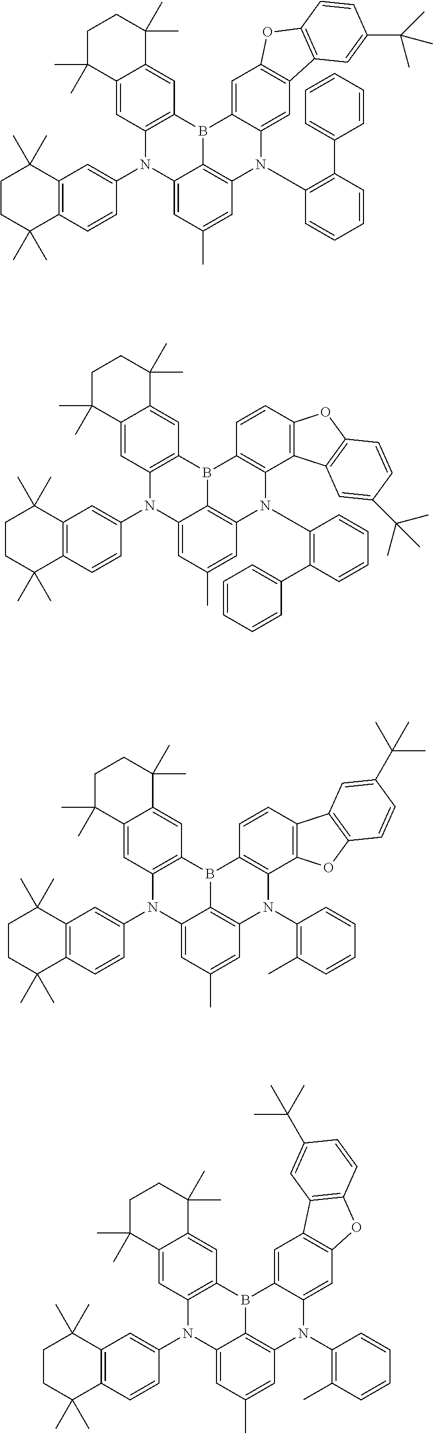 [SMILES: Cc1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1cc2c3c(c1)N(c1ccccc1C)c1c(ccc4c1oc1ccc(C(C)(C)C)cc14)B3c1cc3c(cc1N2c1ccc2c(c1)C(C)(C)CCC2(C)C)C(C)(C)CCC3(C)C ; Cc1cc2c3c(c1)N(c1ccccc1C)c1cc4oc5ccc(C(C)(C)C)cc5c4cc1B3c1cc3c(cc1N2c1ccc2c(c1)C(C)(C)CCC2(C)C)C(C)(C)CCC3(C)C]

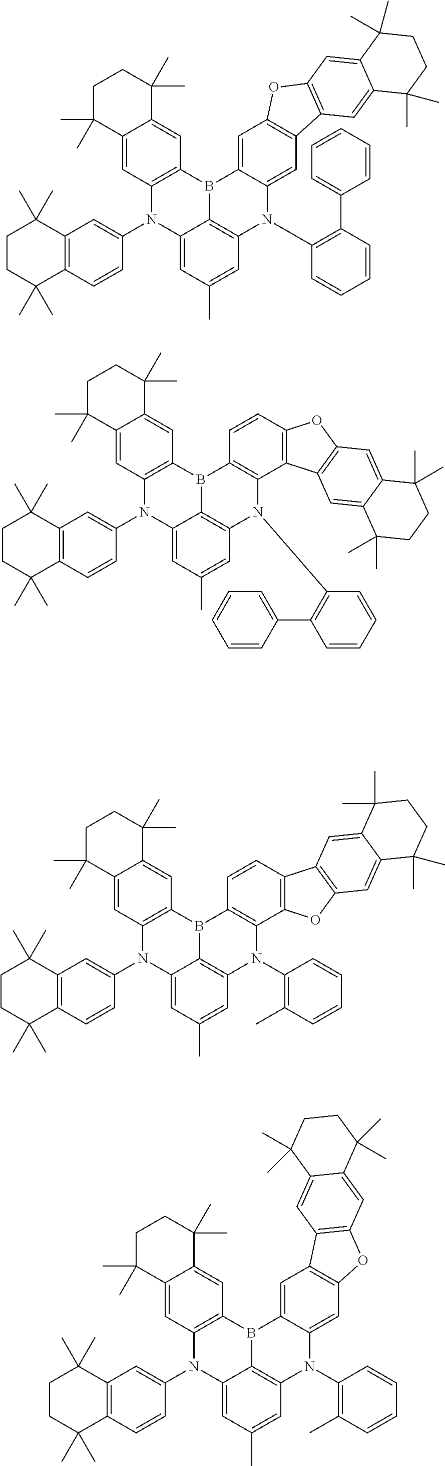

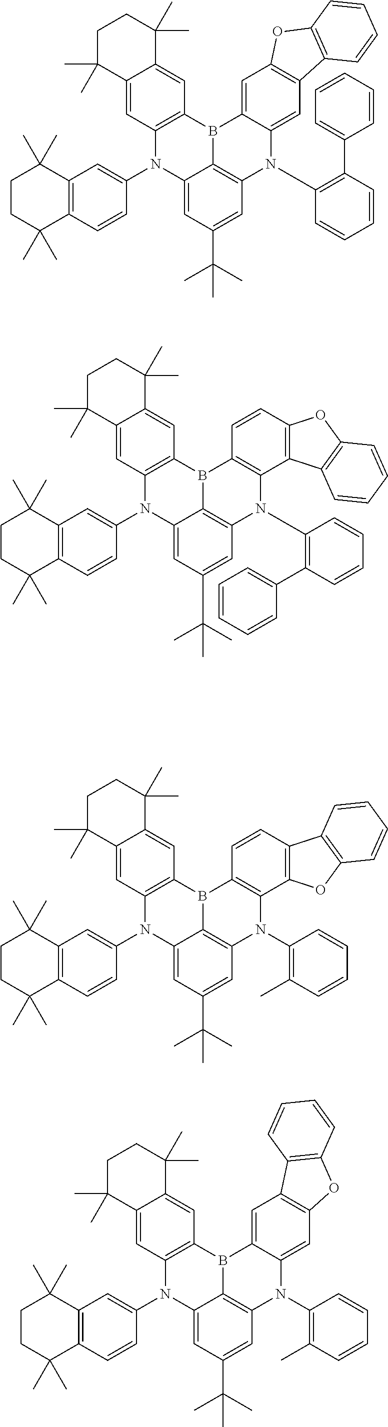 [SMILES: CC(C)(C)c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccccc14 ; CC(C)(C)c1cc2c3c(c1)N(c1ccccc1-c1ccccc1)c1c(ccc4oc5ccccc5c14)B3c1cc3c(cc1N2c1ccc2c(c1)C(C)(C)CCC2(C)C)C(C)(C)CCC3(C)C ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3c(oc4ccccc43)c21 ; Cc1ccccc1N1c2cc3oc4ccccc4c3cc2B2c3cc4c(cc3N(c3ccc5c(c3)C(C)(C)CCC5(C)C)c3cc(C(C)(C)C)cc1c32)C(C)(C)CCC4(C)C]

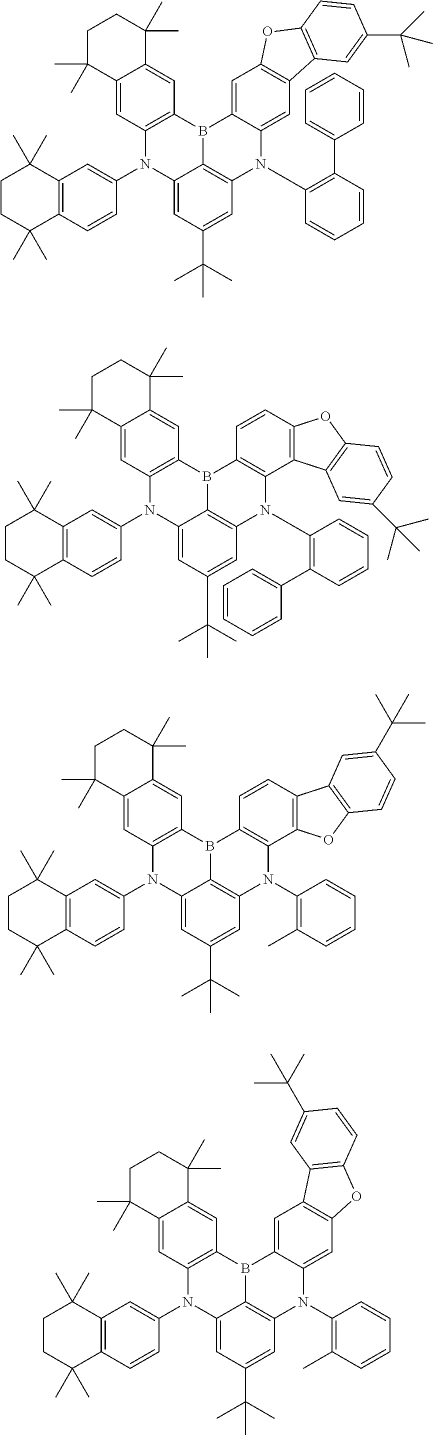 [SMILES: CC(C)(C)c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; CC(C)(C)c1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)CCC5(C)C)c3cc(C(C)(C)C)cc1c32)C(C)(C)CCC4(C)C]

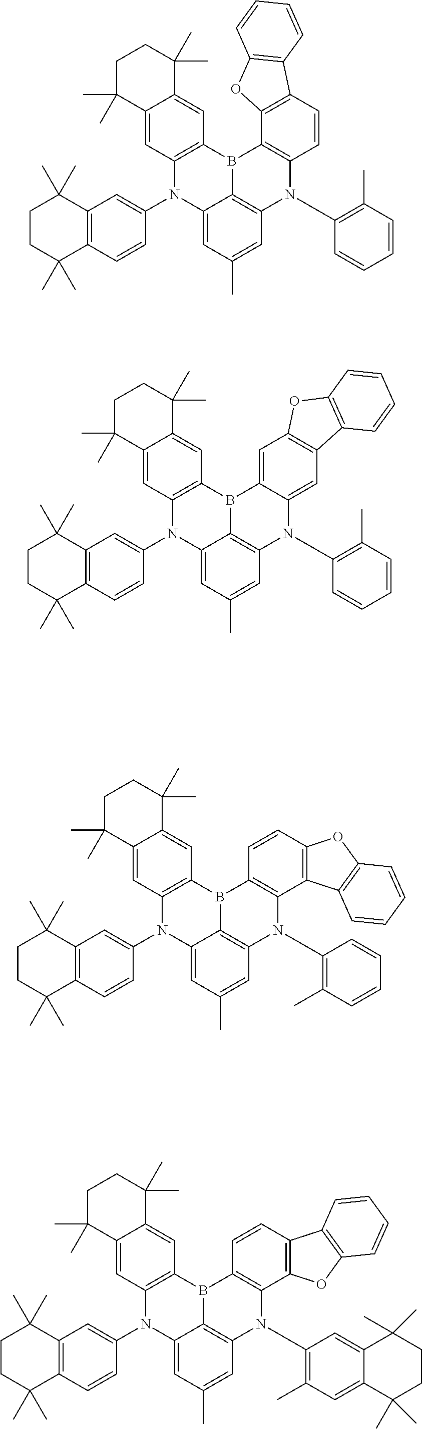 [SMILES: Cc1cc2c3c(c1)N(c1ccccc1C)c1ccc4c(oc5ccccc54)c1B3c1cc3c(cc1N2c1ccc2c(c1)C(C)(C)CCC2(C)C)C(C)(C)CCC3(C)C ; Cc1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1ccccc14 ; Cc1cc2c3c(c1)N(c1ccccc1C)c1c(ccc4oc5ccccc5c14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1c(ccc4c1oc1ccccc14)B3c1cc3c(cc1N2c1ccc2c(c1)C(C)(C)CCC2(C)C)C(C)(C)CCC3(C)C]

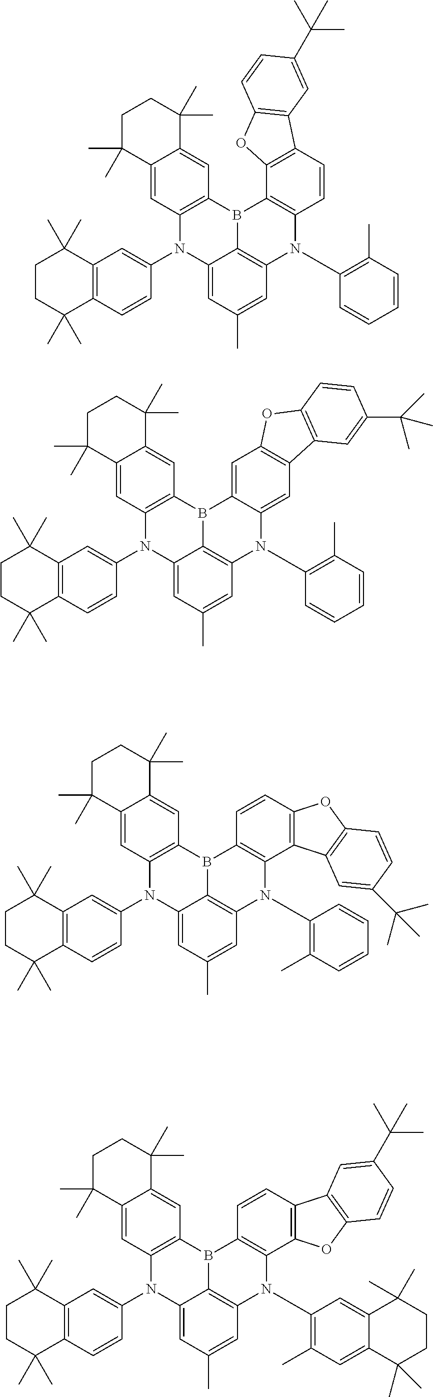 [SMILES: Cc1cc2c3c(c1)N(c1ccccc1C)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1cc2c3c(c1)N(c1ccccc1C)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1c(ccc4c1oc1ccc(C(C)(C)C)cc14)B3c1cc3c(cc1N2c1ccc2c(c1)C(C)(C)CCC2(C)C)C(C)(C)CCC3(C)C]

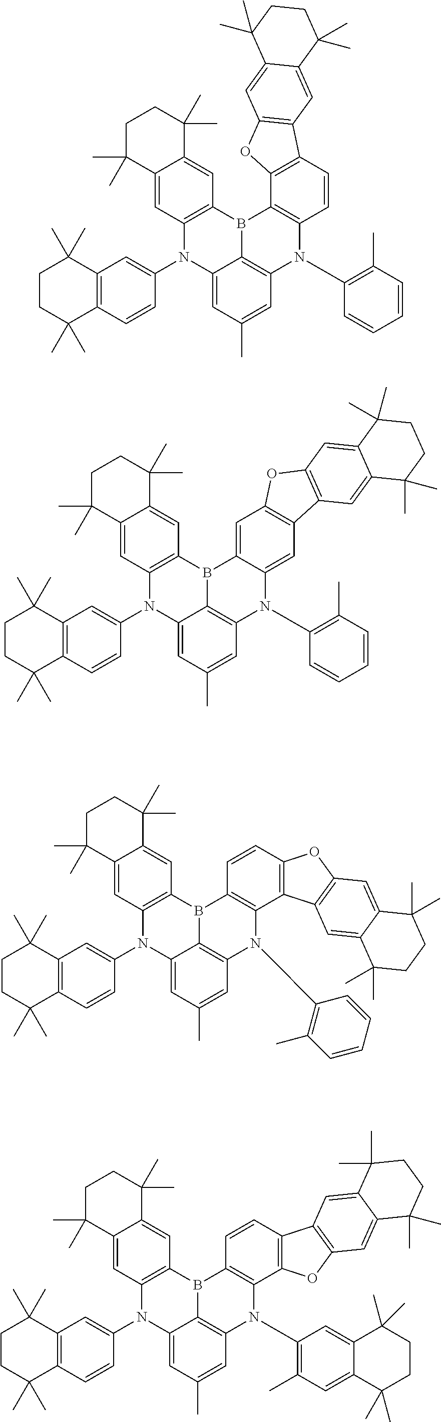

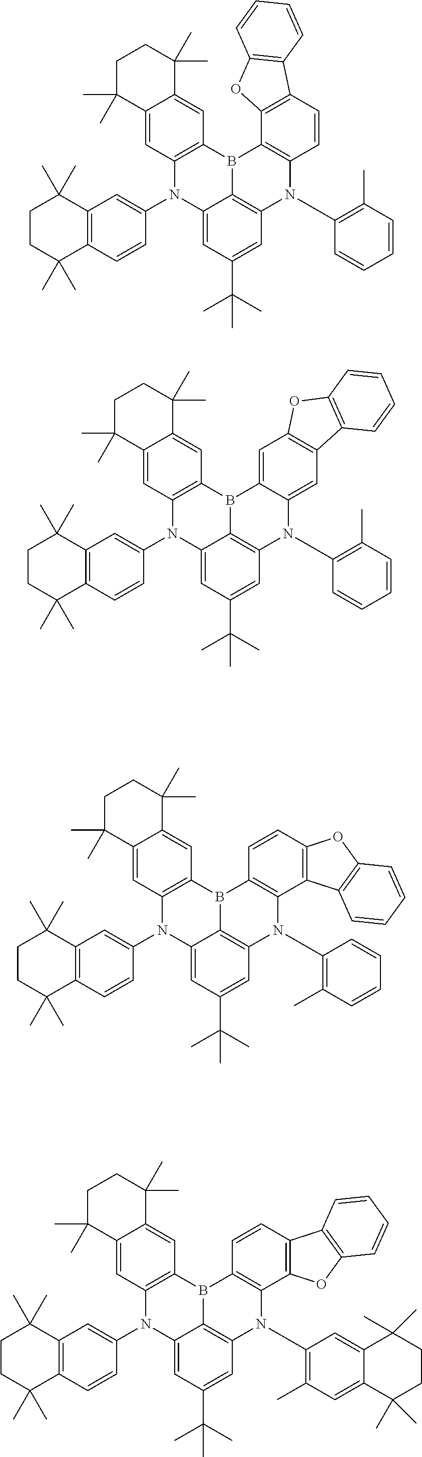 [SMILES: Cc1ccccc1N1c2cc(C(C)(C)C)cc3c2B(c2cc4c(cc2N3c2ccc3c(c2)C(C)(C)CCC3(C)C)C(C)(C)CCC4(C)C)c2c1ccc1c2oc2ccccc21 ; Cc1ccccc1N1c2cc3c(cc2B2c4cc5c(cc4N(c4ccc6c(c4)C(C)(C)CCC6(C)C)c4cc(C(C)(C)C)cc1c42)C(C)(C)CCC5(C)C)oc1ccccc13 ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3oc4ccccc4c3c21 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5ccccc54)c31)C(C)(C)CCC2(C)C]

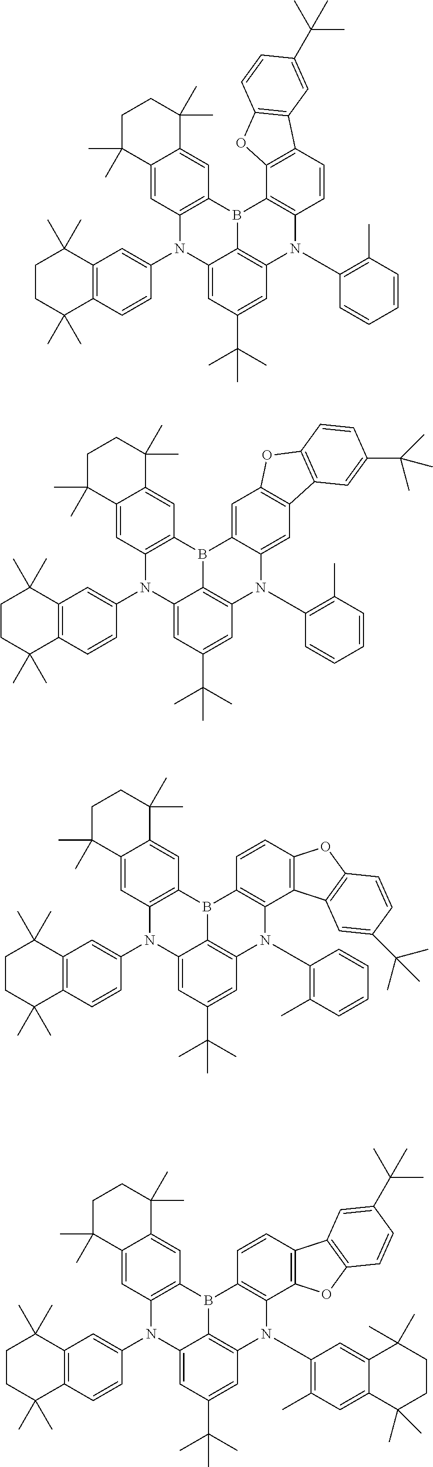 [SMILES: Cc1ccccc1N1c2cc(C(C)(C)C)cc3c2B(c2cc4c(cc2N3c2ccc3c(c2)C(C)(C)CCC3(C)C)C(C)(C)CCC4(C)C)c2c1ccc1c2oc2ccc(C(C)(C)C)cc21 ; Cc1ccccc1N1c2cc3c(cc2B2c4cc5c(cc4N(c4ccc6c(c4)C(C)(C)CCC6(C)C)c4cc(C(C)(C)C)cc1c42)C(C)(C)CCC5(C)C)oc1ccc(C(C)(C)C)cc13 ; Cc1ccccc1N1c2cc(C(C)(C)C)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C]

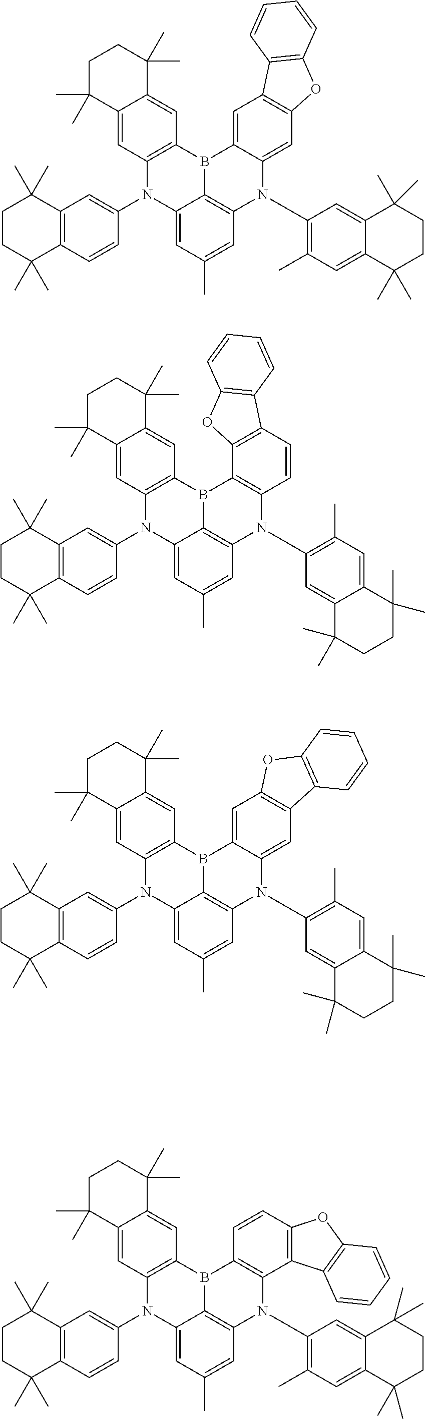

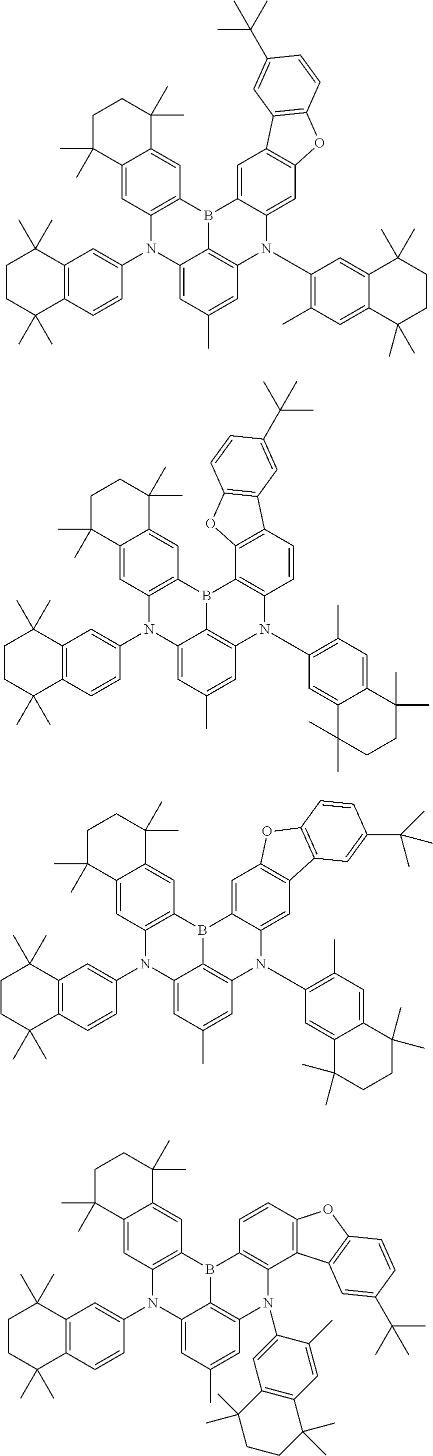

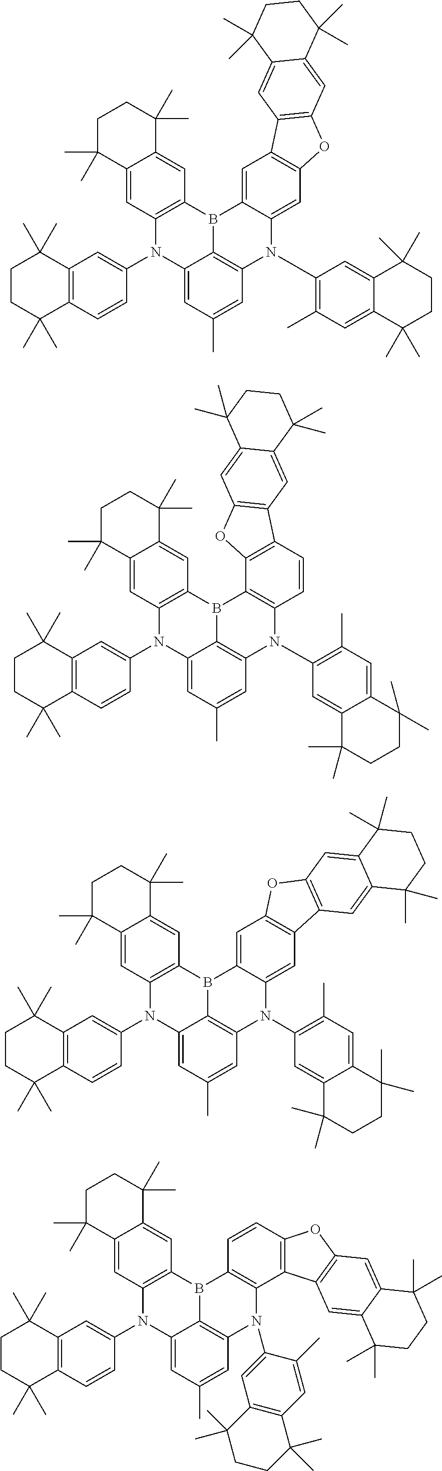

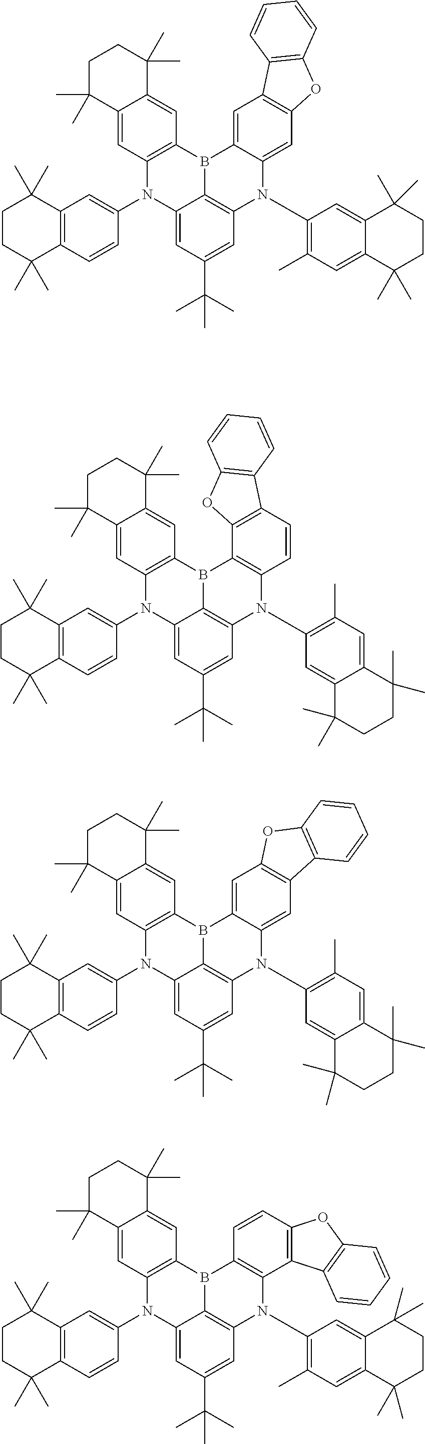

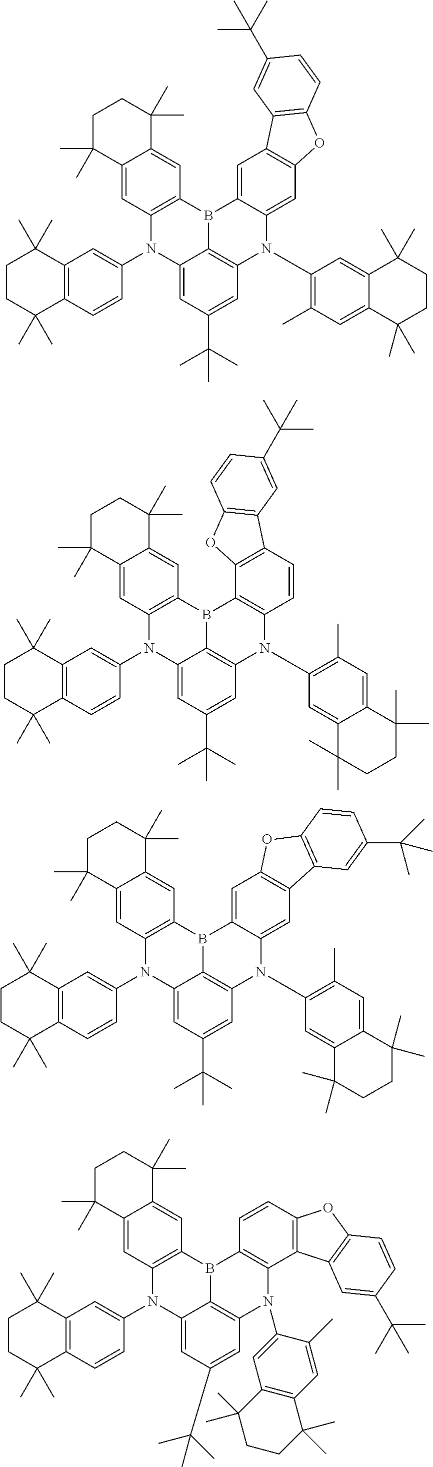

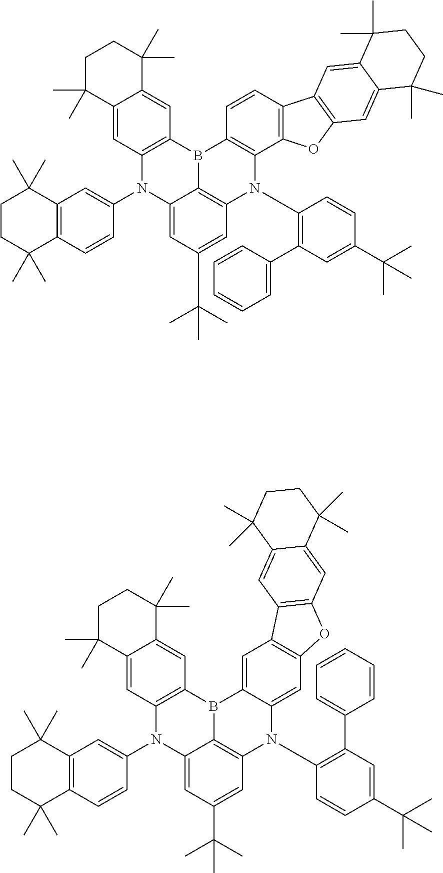 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c32)c(-c2ccccc2)c1 ; CC(C)(C)c1ccc(N2c3cc4oc5cc6c(cc5c4cc3B3c4cc5c(cc4N(c4ccc7c(c4)C(C)(C)CCC7(C)C)c4cc(C(C)(C)C)cc2c43)C(C)(C)CCC5(C)C)C(C)(C)CCC6(C)C)c(-c2ccccc2)c1]

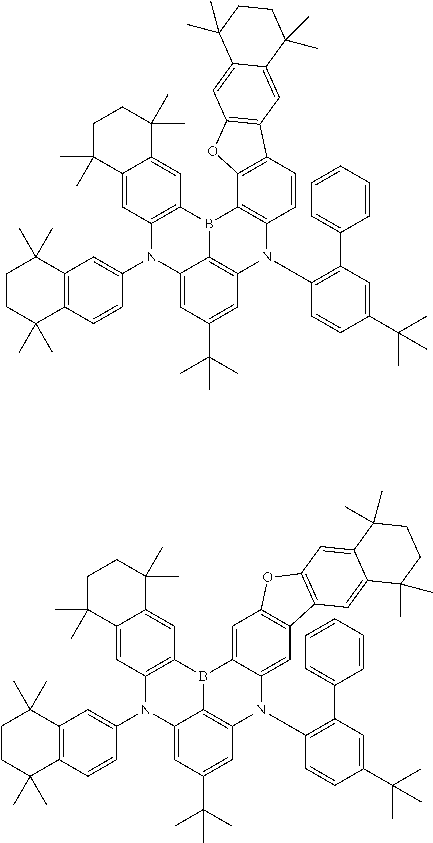 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3c2ccc2c3oc3cc4c(cc32)C(C)(C)CCC4(C)C)c(-c2ccccc2)c1 ; CC(C)(C)c1ccc(N2c3cc4c(cc3B3c5cc6c(cc5N(c5ccc7c(c5)C(C)(C)CCC7(C)C)c5cc(C(C)(C)C)cc2c53)C(C)(C)CCC6(C)C)oc2cc3c(cc24)C(C)(C)CCC3(C)C)c(-c2ccccc2)c1]

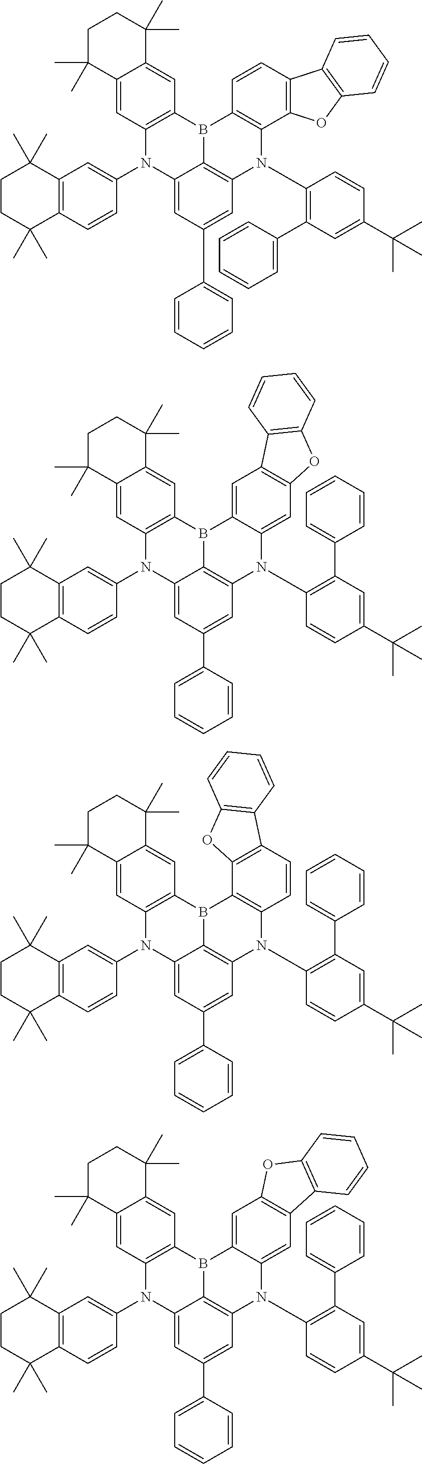

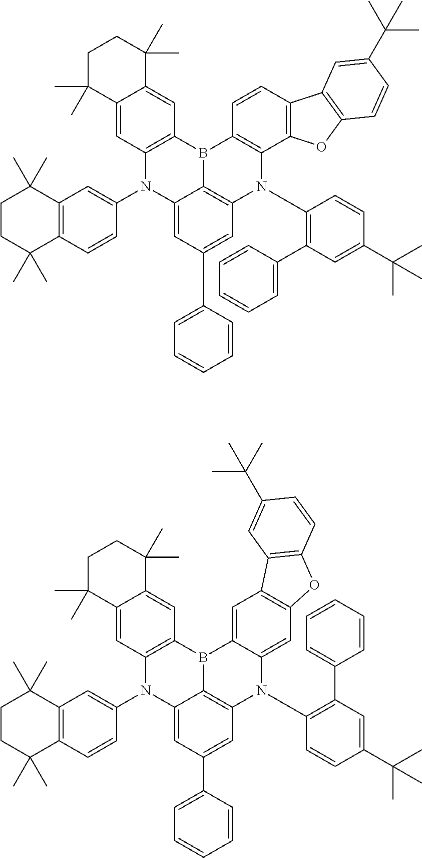 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c32)c(-c2ccccc2)c1 ; CC(C)(C)c1ccc(N2c3cc4oc5ccc(C(C)(C)C)cc5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1]

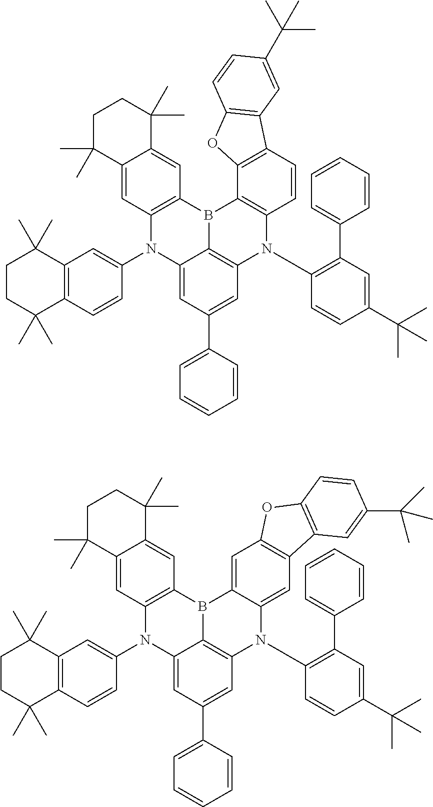 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3oc3ccc(C(C)(C)C)cc32)c(-c2ccccc2)c1 ; CC(C)(C)c1ccc(N2c3cc4c(cc3B3c5cc6c(cc5N(c5ccc7c(c5)C(C)(C)CCC7(C)C)c5cc(-c7ccccc7)cc2c53)C(C)(C)CCC6(C)C)oc2ccc(C(C)(C)C)cc24)c(-c2ccccc2)c1]

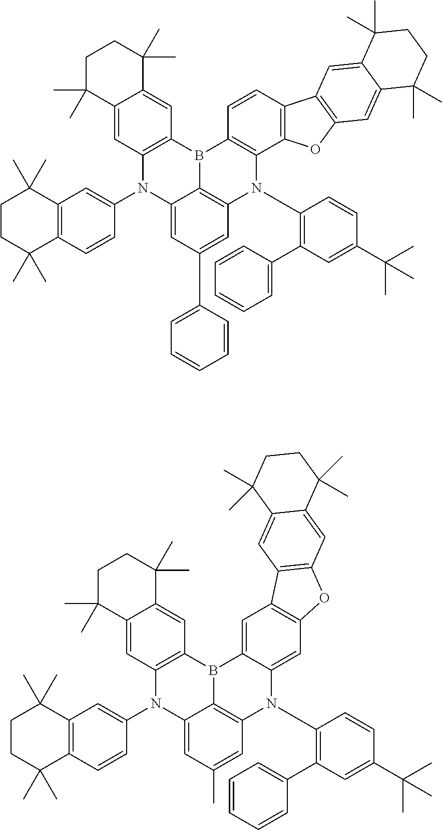 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c32)c(-c2ccccc2)c1 ; Cc1cc2c3c(c1)N(c1ccc(C(C)(C)C)cc1-c1ccccc1)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C]

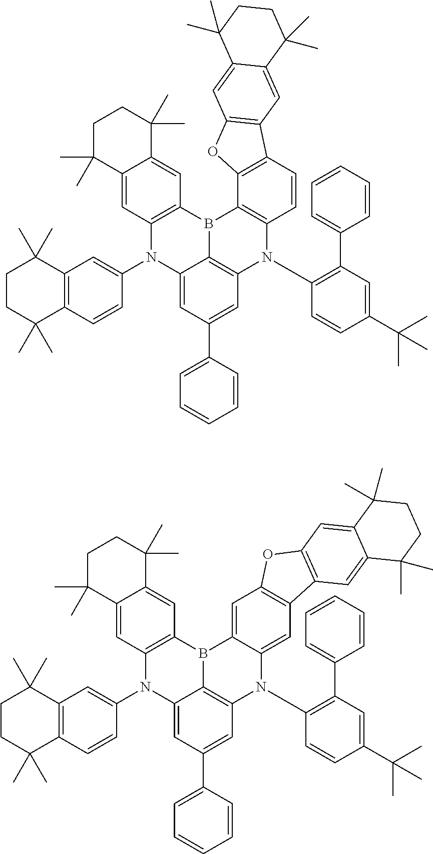 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3oc3cc4c(cc32)C(C)(C)CCC4(C)C)c(-c2ccccc2)c1 ; CC(C)(C)c1ccc(N2c3cc4c(cc3B3c5cc6c(cc5N(c5ccc7c(c5)C(C)(C)CCC7(C)C)c5cc(-c7ccccc7)cc2c53)C(C)(C)CCC6(C)C)oc2cc3c(cc24)C(C)(C)CCC3(C)C)c(-c2ccccc2)c1]

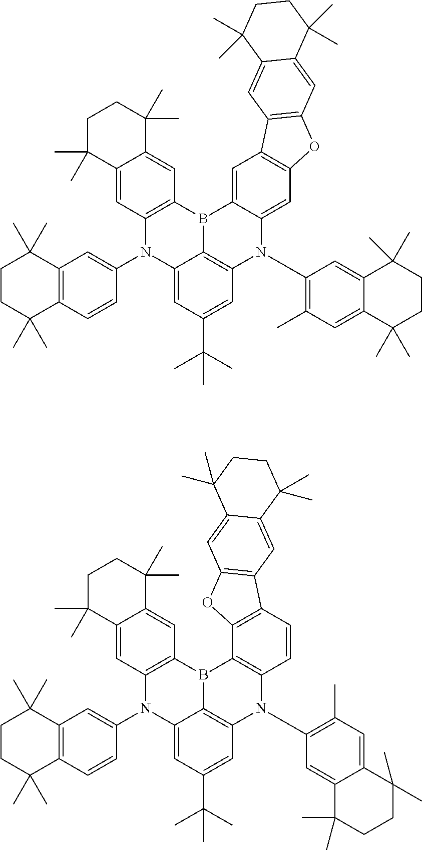 [SMILES: Cc1cc2c(cc1N1c3cc4oc5cc6c(cc5c4cc3B3c4cc5c(cc4N(c4ccc7c(c4)C(C)(C)CCC7(C)C)c4cc(C(C)(C)C)cc1c43)C(C)(C)CCC5(C)C)C(C)(C)CCC6(C)C)C(C)(C)CCC2(C)C ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3c1ccc1c3oc3cc4c(cc31)C(C)(C)CCC4(C)C)C(C)(C)CCC2(C)C]

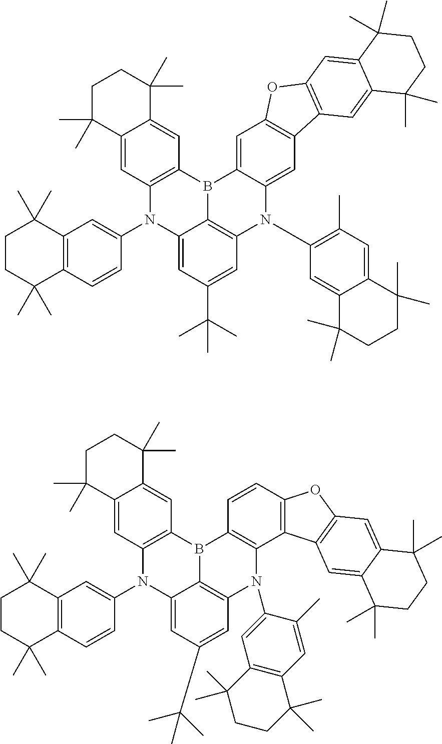 [SMILES: Cc1cc2c(cc1N1c3cc4c(cc3B3c5cc6c(cc5N(c5ccc7c(c5)C(C)(C)CCC7(C)C)c5cc(C(C)(C)C)cc1c53)C(C)(C)CCC6(C)C)oc1cc3c(cc14)C(C)(C)CCC3(C)C)C(C)(C)CCC2(C)C ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4oc5cc6c(cc5c4c31)C(C)(C)CCC6(C)C)C(C)(C)CCC2(C)C]

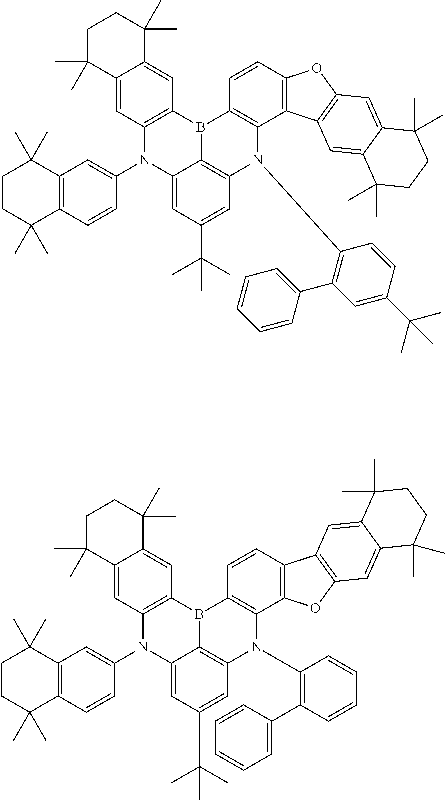 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3ccc4oc5cc6c(cc5c4c32)C(C)(C)CCC6(C)C)c(-c2ccccc2)c1 ; CC(C)(C)c1cc2c3c(c1)N(c1ccccc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C]

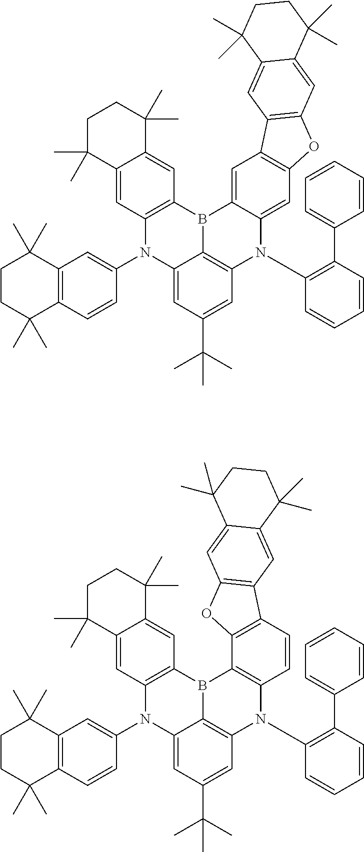 [SMILES: CC(C)(C)c1cc2c3c(c1)N(c1ccccc1-c1ccccc1)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C ; CC(C)(C)c1cc2c3c(c1)N(c1ccccc1-c1ccccc1)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C]

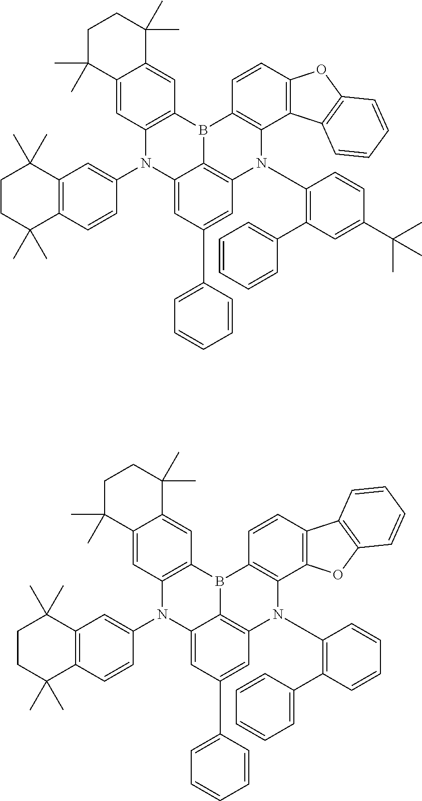 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4oc5ccccc5c4c32)c(-c2ccccc2)c1 ; CC1(C)CCC(C)(C)c2cc(N3c4cc5c(cc4B4c6ccc7c(oc8ccccc87)c6N(c6ccccc6-c6ccccc6)c6cc(-c7ccccc7)cc3c64)C(C)(C)CCC5(C)C)ccc21]

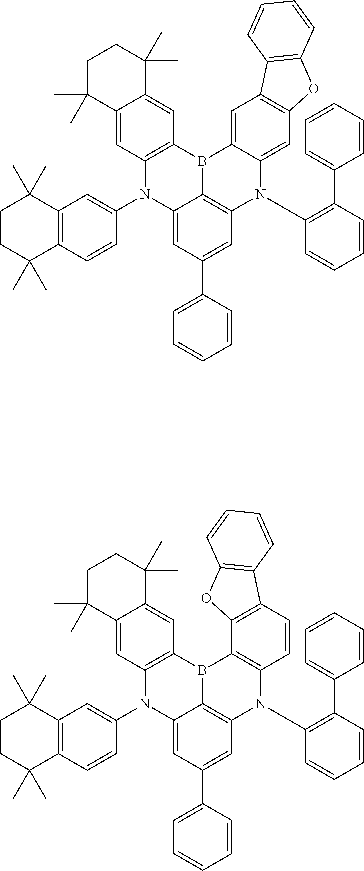 [SMILES: CC1(C)CCC(C)(C)c2cc(N3c4cc5c(cc4B4c6cc7c(cc6N(c6ccccc6-c6ccccc6)c6cc(-c8ccccc8)cc3c64)oc3ccccc37)C(C)(C)CCC5(C)C)ccc21 ; CC1(C)CCC(C)(C)c2cc(N3c4cc5c(cc4B4c6c3cc(-c3ccccc3)cc6N(c3ccccc3-c3ccccc3)c3ccc6c(oc7ccccc76)c34)C(C)(C)CCC5(C)C)ccc21]

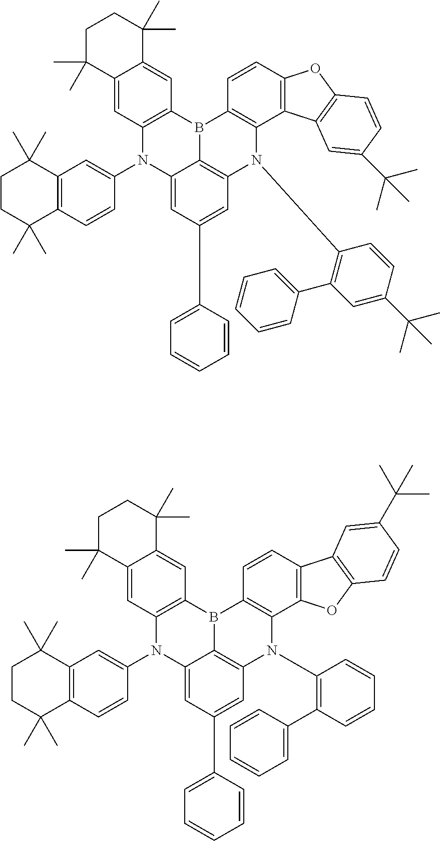 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4oc5ccc(C(C)(C)C)cc5c4c32)c(-c2ccccc2)c1 ; CC(C)(C)c1ccc2oc3c4c(ccc3c2c1)B1c2cc3c(cc2N(c2ccc5c(c2)C(C)(C)CCC5(C)C)c2cc(-c5ccccc5)cc(c21)N4c1ccccc1-c1ccccc1)C(C)(C)CCC3(C)C]

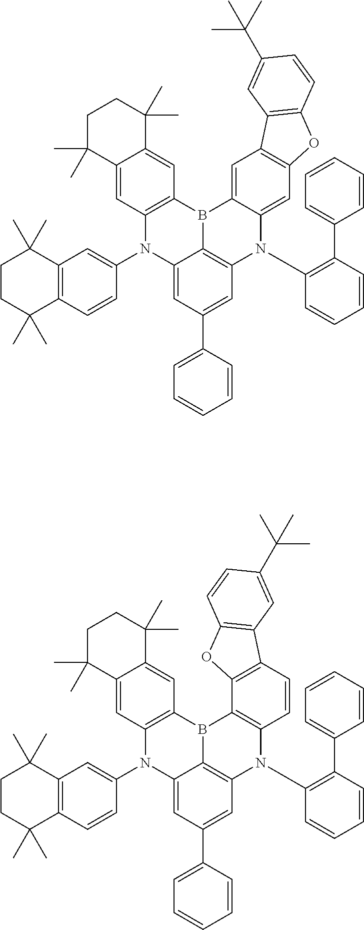 [SMILES: CC(C)(C)c1ccc2oc3cc4c(cc3c2c1)B1c2cc3c(cc2N(c2ccc5c(c2)C(C)(C)CCC5(C)C)c2cc(-c5ccccc5)cc(c21)N4c1ccccc1-c1ccccc1)C(C)(C)CCC3(C)C ; CC(C)(C)c1ccc2oc3c4c(ccc3c2c1)N(c1ccccc1-c1ccccc1)c1cc(-c2ccccc2)cc2c1B4c1cc3c(cc1N2c1ccc2c(c1)C(C)(C)CCC2(C)C)C(C)(C)CCC3(C)C]

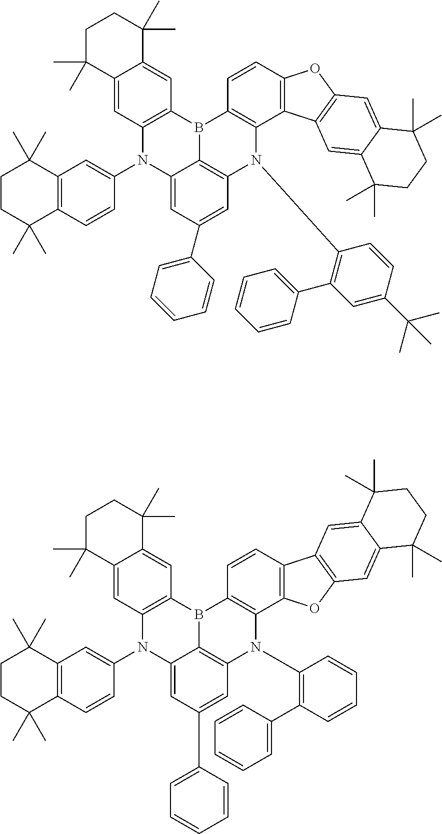 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4oc5cc6c(cc5c4c32)C(C)(C)CCC6(C)C)c(-c2ccccc2)c1 ; CC1(C)CCC(C)(C)c2cc(N3c4cc5c(cc4B4c6ccc7c(oc8cc9c(cc87)C(C)(C)CCC9(C)C)c6N(c6ccccc6-c6ccccc6)c6cc(-c7ccccc7)cc3c64)C(C)(C)CCC5(C)C)ccc21]

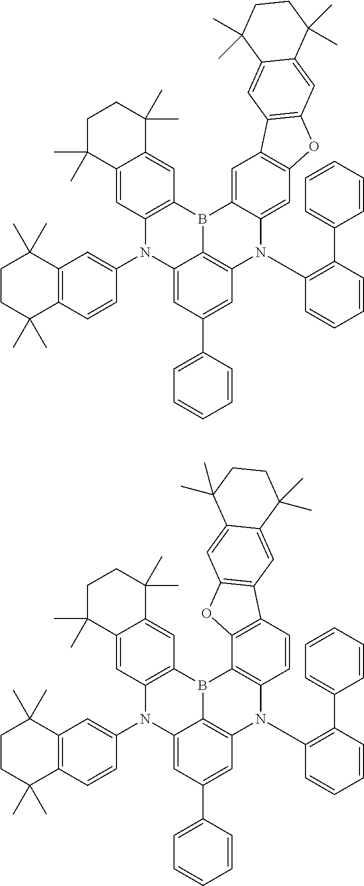

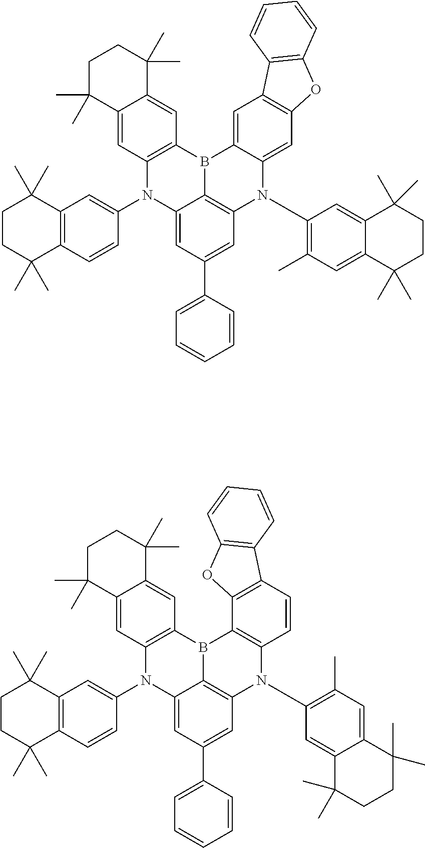 [SMILES: Cc1cc2c(cc1N1c3cc4oc5ccccc5c4cc3B3c4cc5c(cc4N(c4ccc6c(c4)C(C)(C)CCC6(C)C)c4cc(-c6ccccc6)cc1c43)C(C)(C)CCC5(C)C)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3c1ccc1c3oc3ccccc31)C(C)(C)CCC2(C)C]

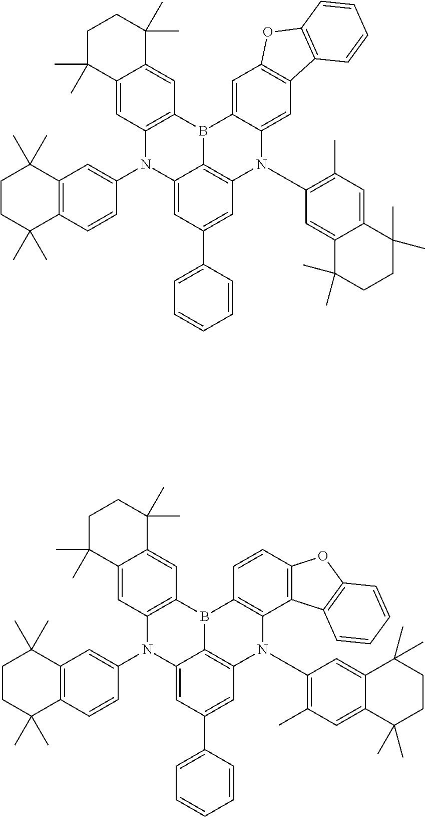 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)oc1ccccc14)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3ccc4oc5ccccc5c4c31)C(C)(C)CCC2(C)C]

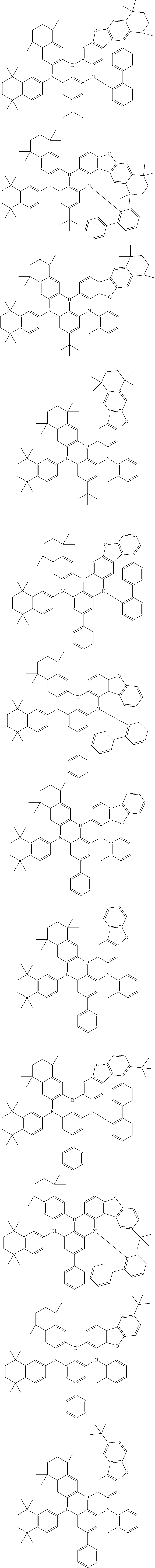

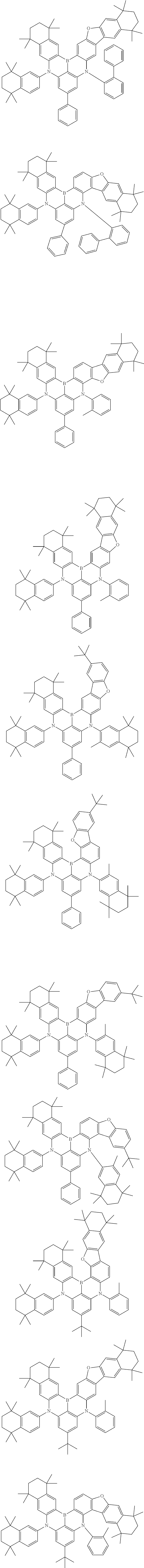

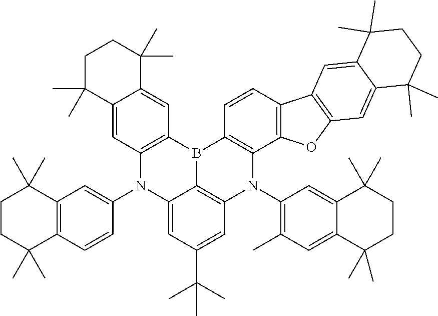 [SMILES: Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c31)C(C)(C)CCC2(C)C]

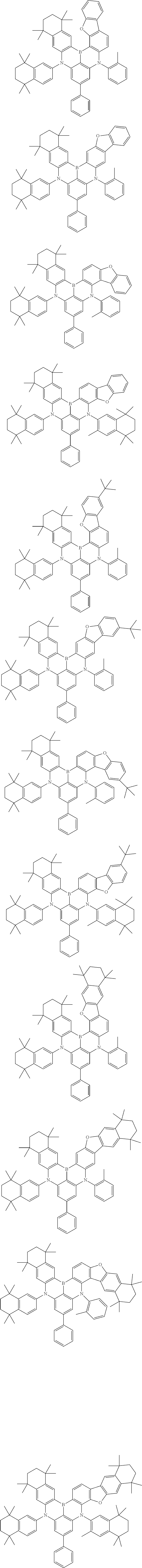

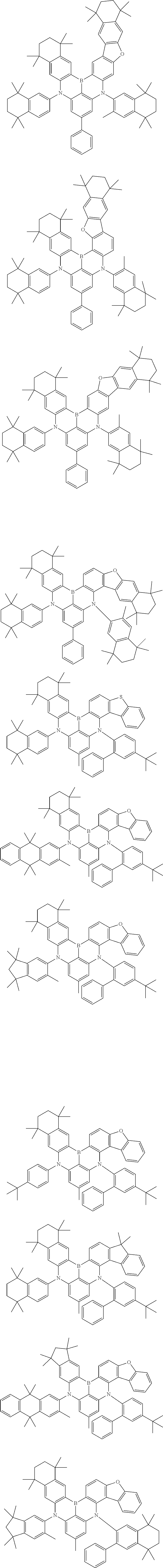

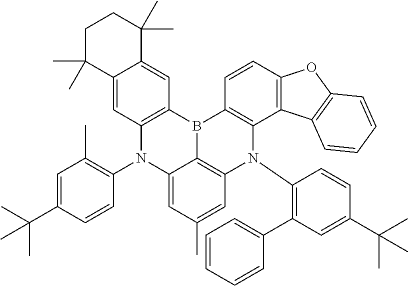 [SMILES: Cc1cc2c3c(c1)N(c1ccc(C(C)(C)C)cc1-c1ccccc1)c1c(ccc4oc5ccccc5c14)B3c1cc3c(cc1N2c1ccc(C(C)(C)C)cc1C)C(C)(C)CCC3(C)C]

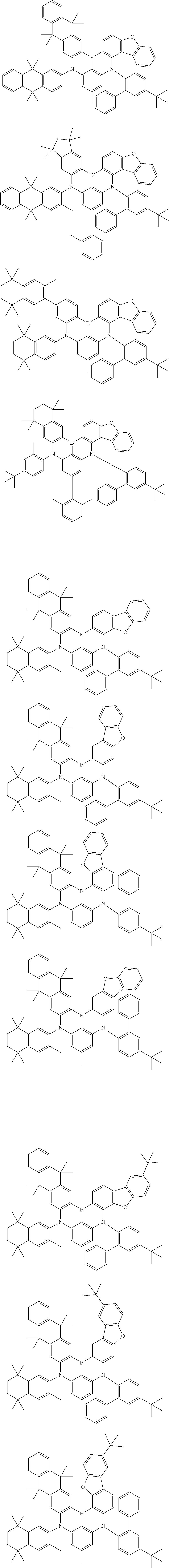

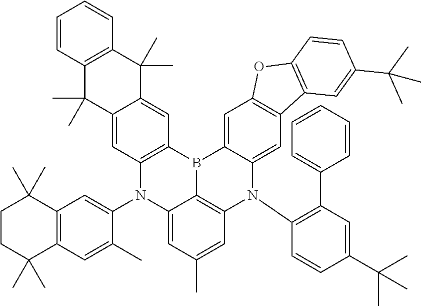 [SMILES: Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14]

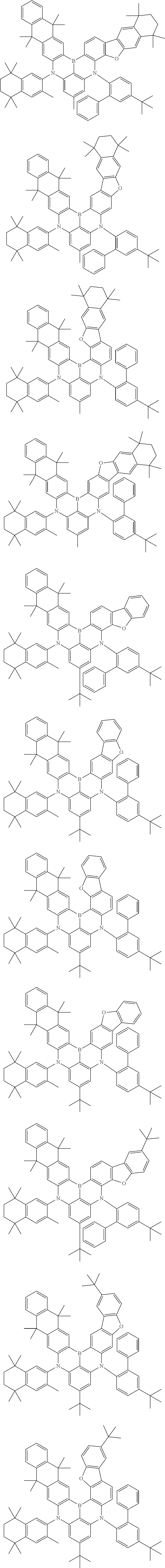

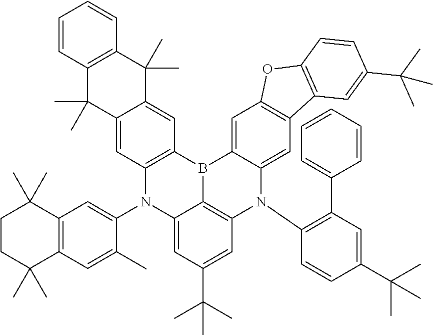 [SMILES: Cc1cc2c(cc1N1c3cc4c(cc3B3c5cc6oc7ccc(C(C)(C)C)cc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C]

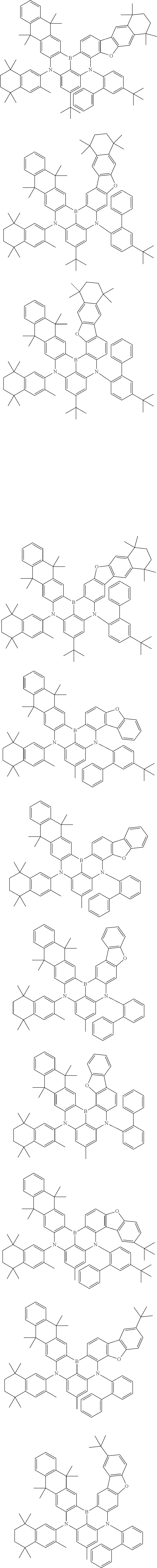

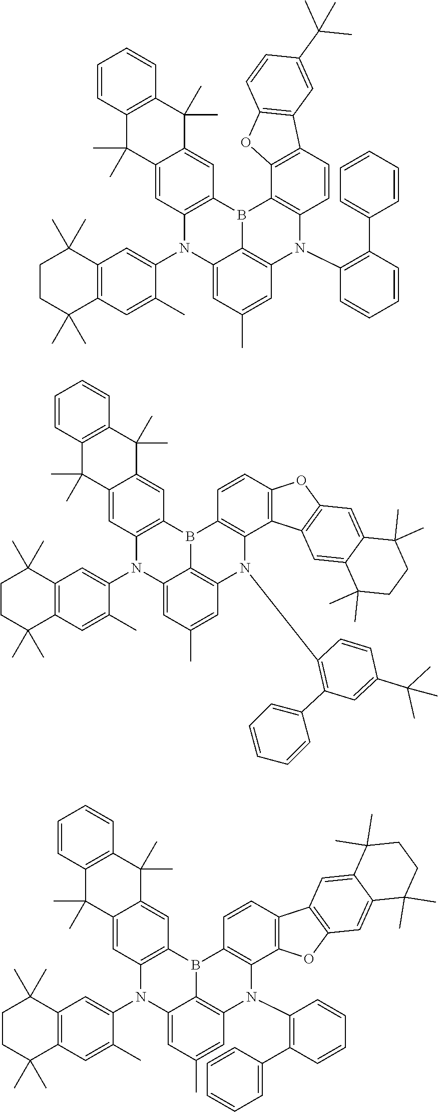

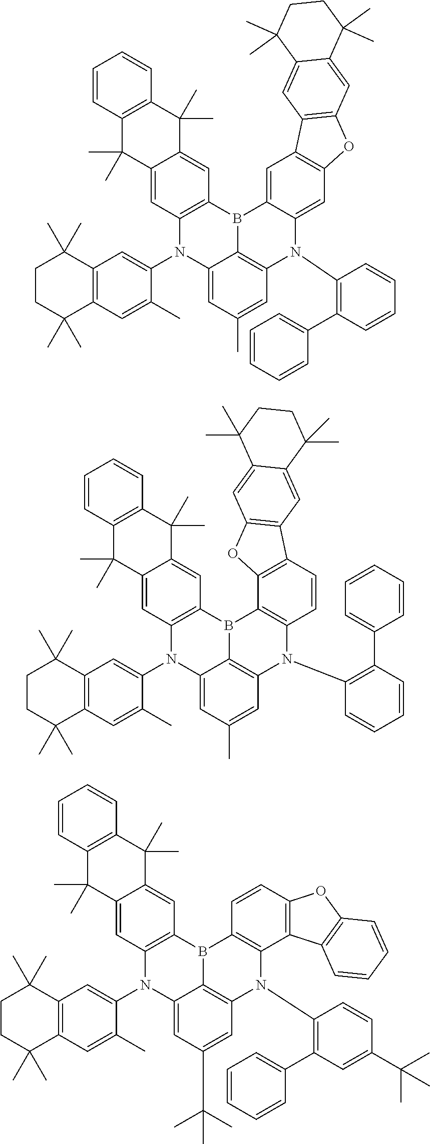

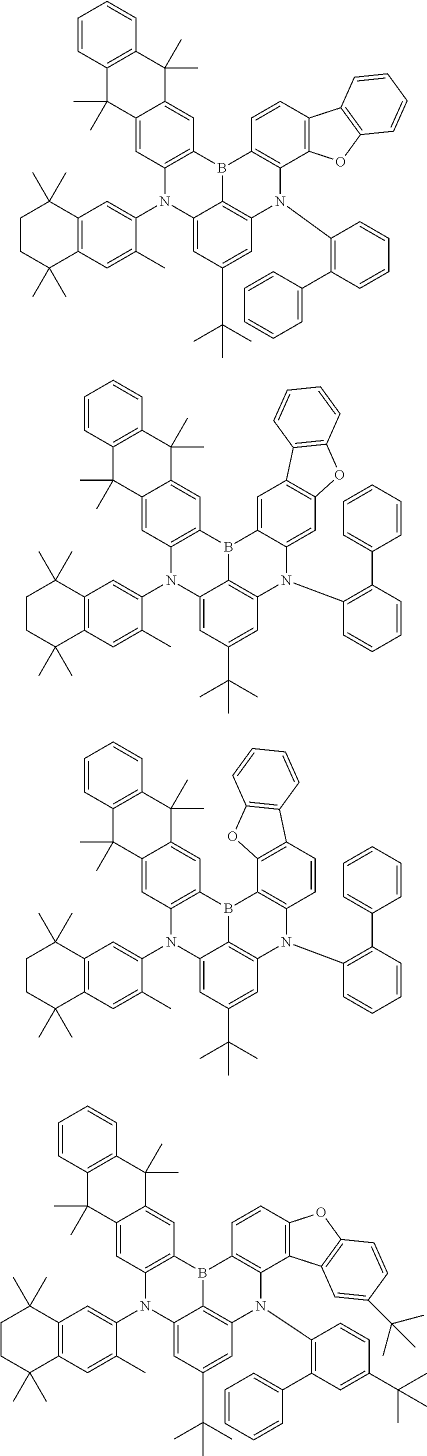

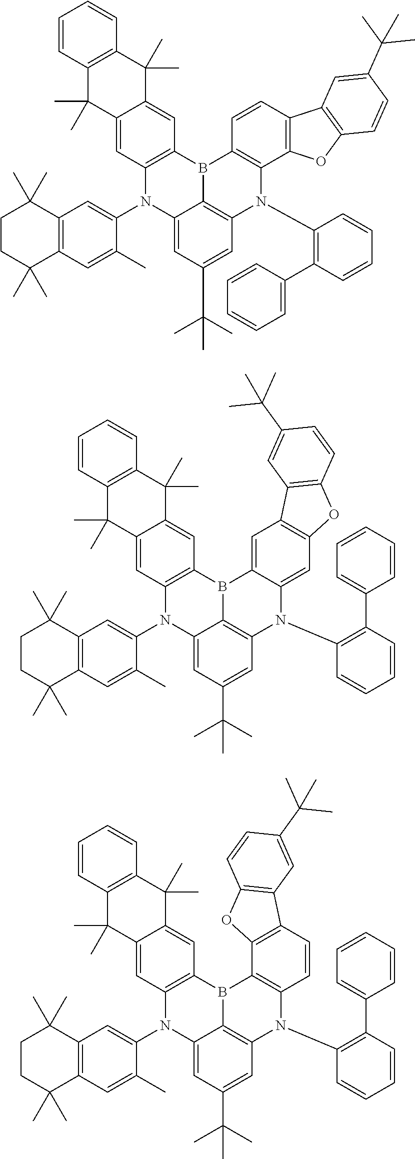

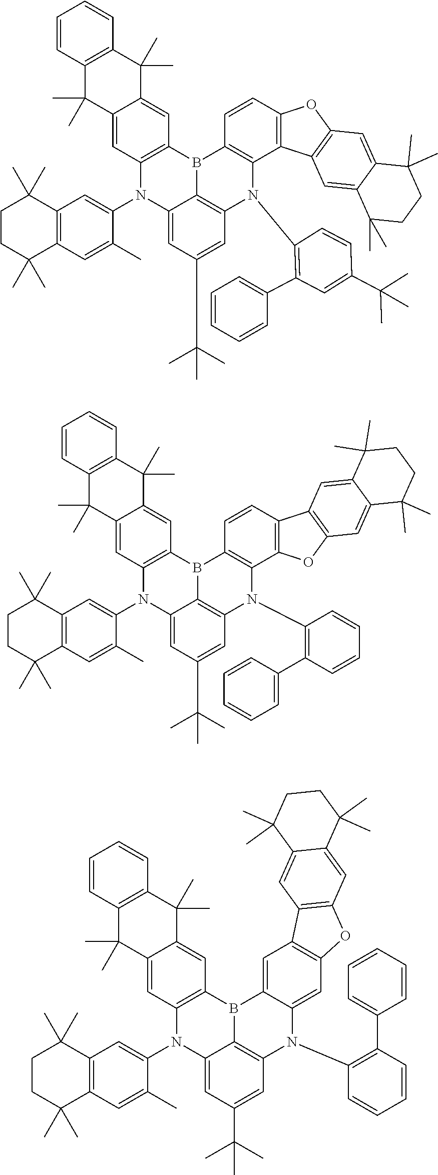 [SMILES: Cc1cc2c(cc1N1c3cc4c(cc3B3c5ccc6oc7cc8c(cc7c6c5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)oc1cc3c(cc16)C(C)(C)CCC3(C)C)C(C)(C)c1ccccc1C4(C)C)C(C)(C)CCC2(C)C]

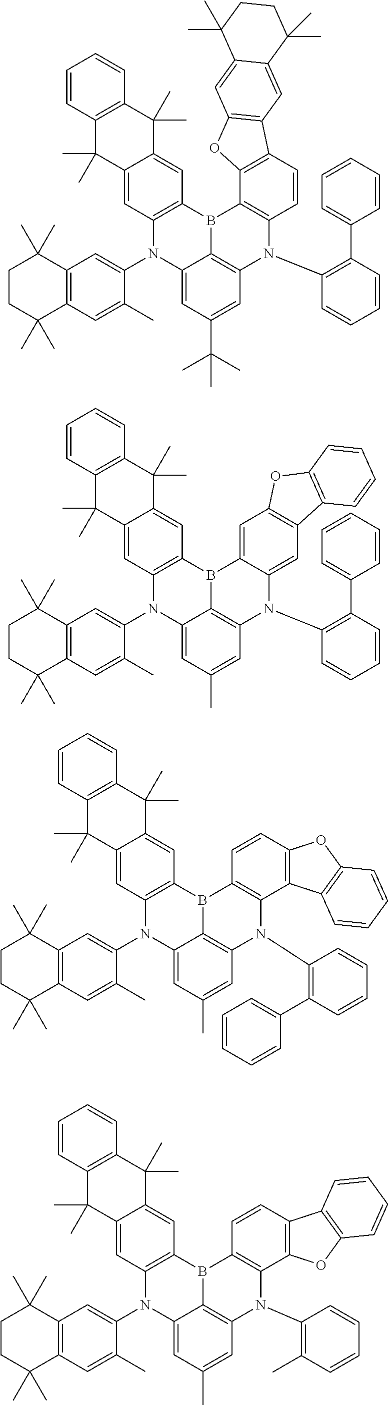

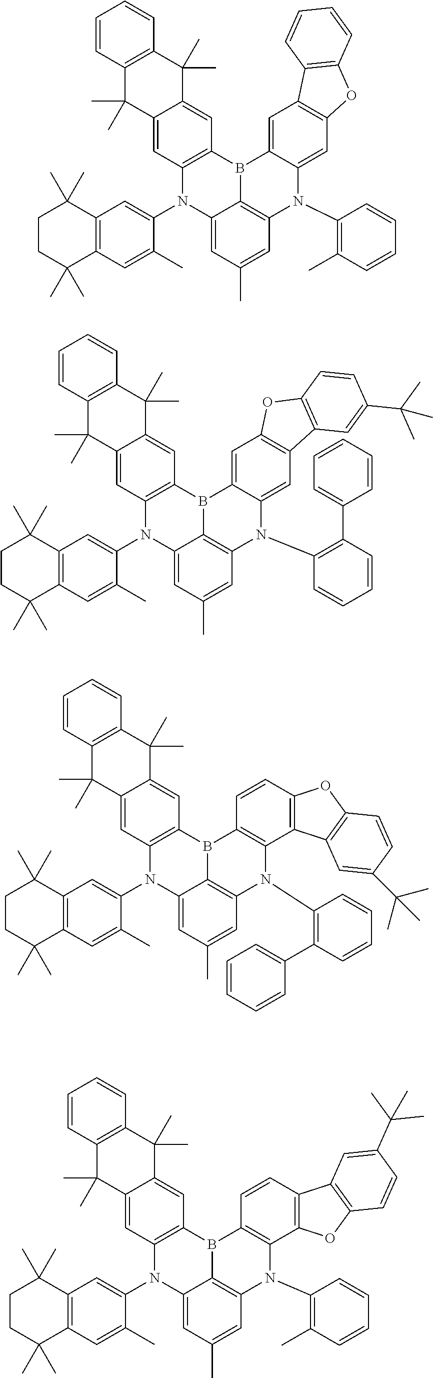

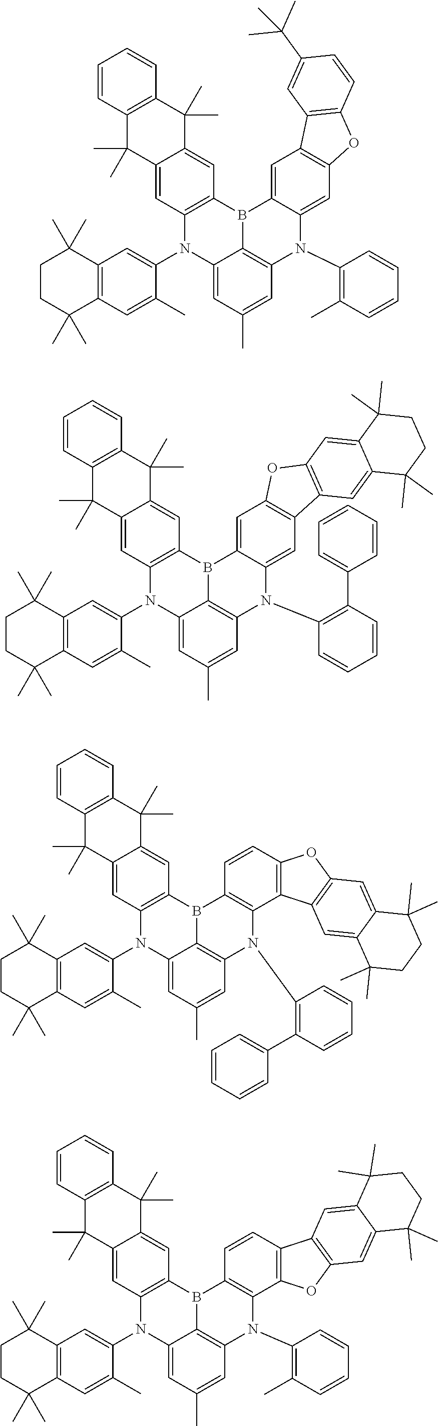

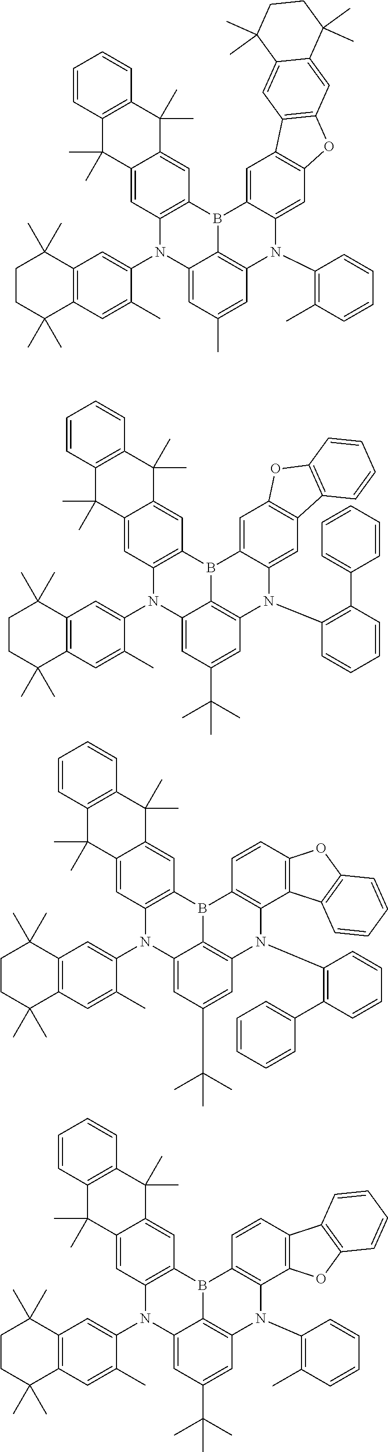 [SMILES: Cc1cc2c3c(c1)N(c1ccccc1C)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1cc2c(cc1N1c3cc4c(cc3B3c5cc6oc7ccccc7c6cc5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5C)c5cc(C(C)(C)C)cc1c53)C(C)(C)c1ccccc1C4(C)C)C(C)(C)CCC2(C)C]

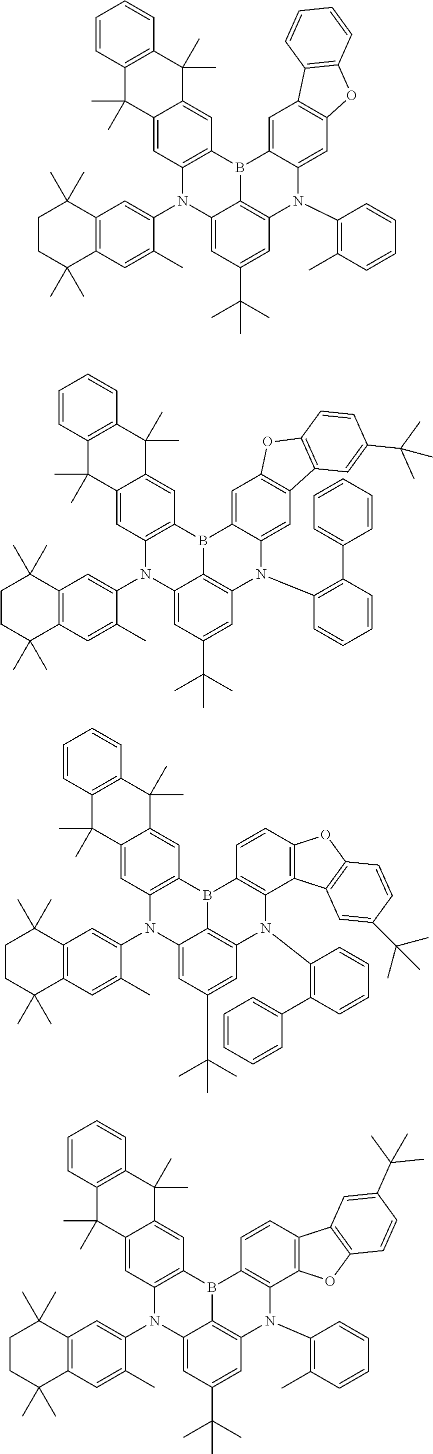

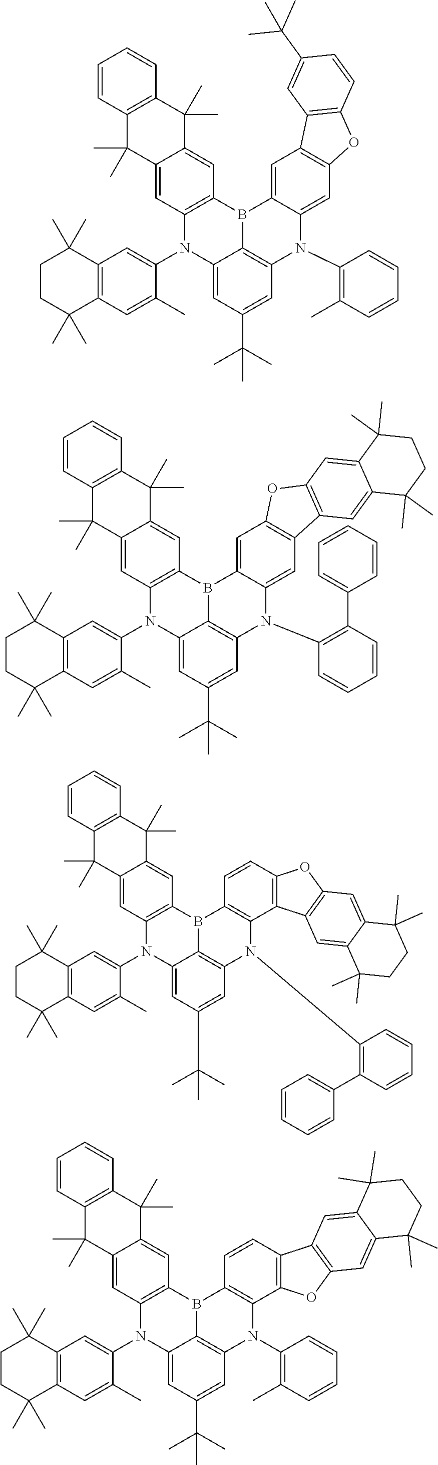

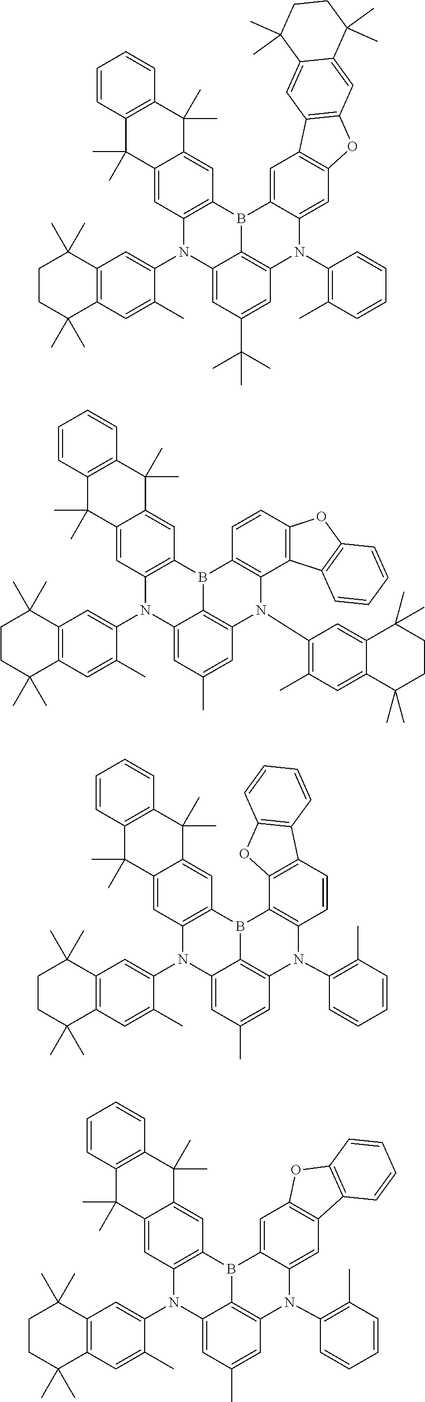 [SMILES: Cc1ccccc1N1c2cc3oc4cc5c(cc4c3cc2B2c3cc4c(cc3N(c3cc6c(cc3C)C(C)(C)CCC6(C)C)c3cc(C(C)(C)C)cc1c32)C(C)(C)c1ccccc1C4(C)C)C(C)(C)CCC5(C)C ; Cc1cc2c3c(c1)N(c1cc4c(cc1C)C(C)(C)CCC4(C)C)c1c(ccc4oc5ccccc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1ccc4c(oc5ccccc54)c1B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1ccccc14]

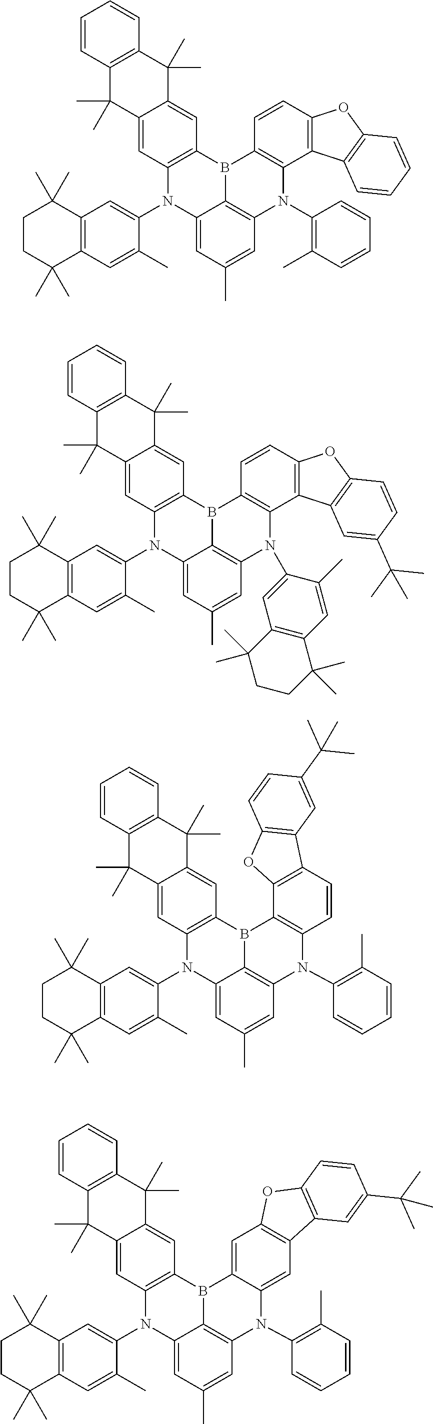

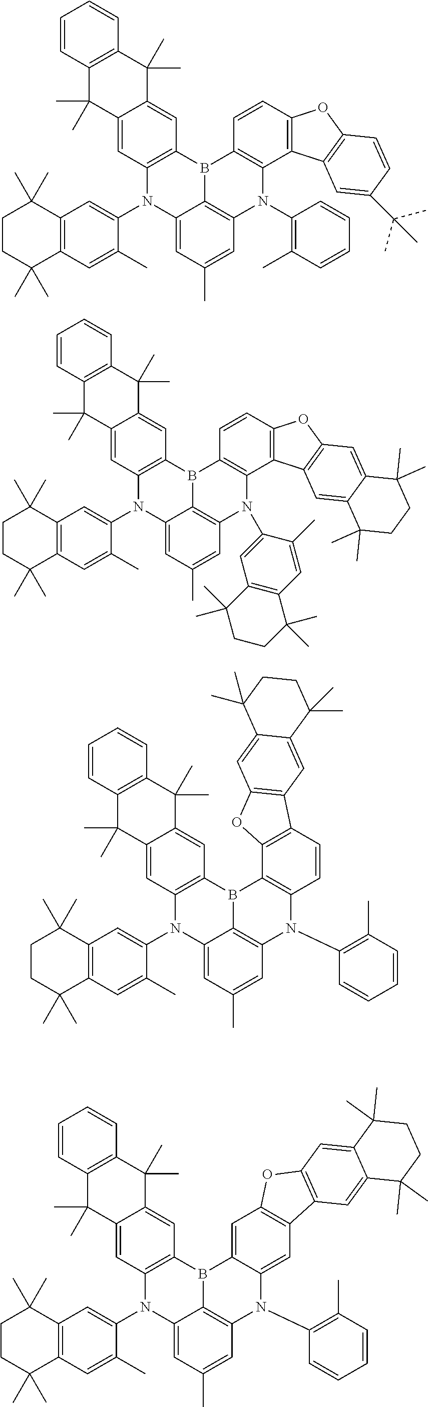

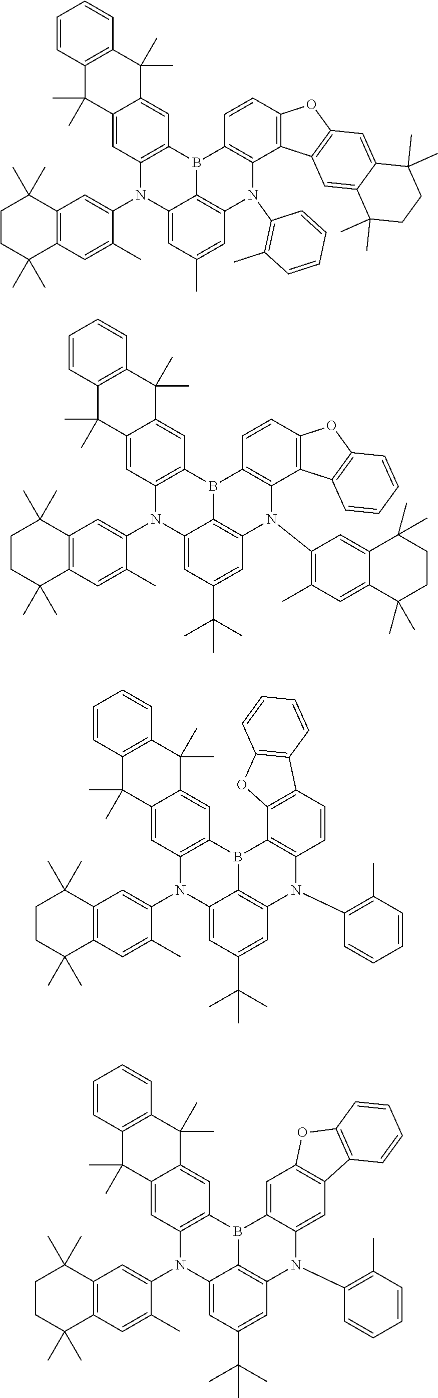 [SMILES: Cc1cc2c3c(c1)N(c1ccccc1C)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1cc2c(cc1N1c3cc4c(cc3B3c5ccc6oc7ccccc7c6c5N(c5cc6c(cc5C)C(C)(C)CCC6(C)C)c5cc(C(C)(C)C)cc1c53)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1C)c1ccc5c(oc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)oc1ccccc13]

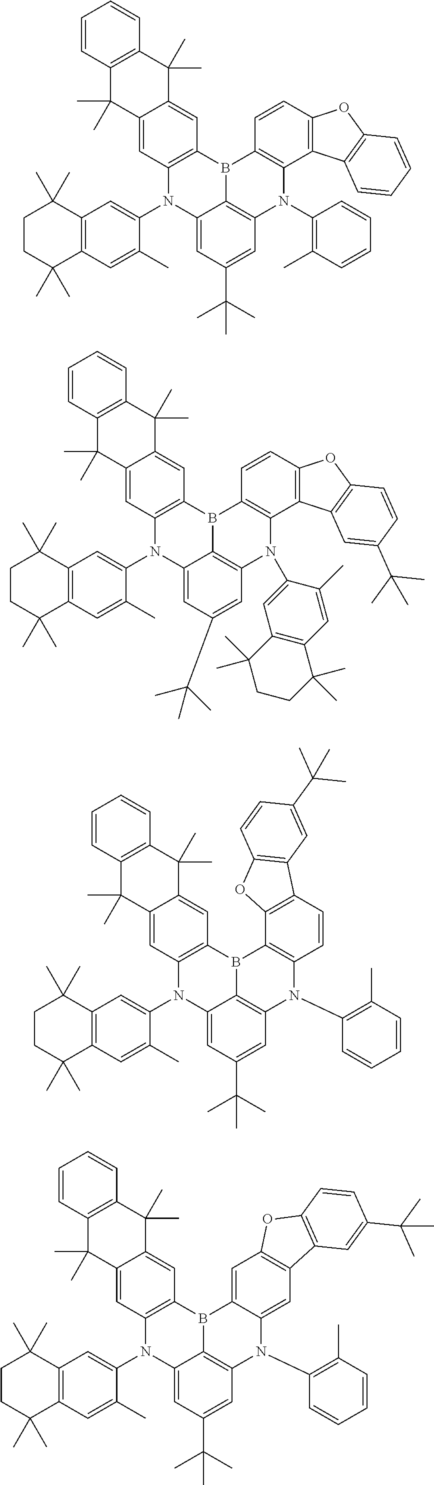

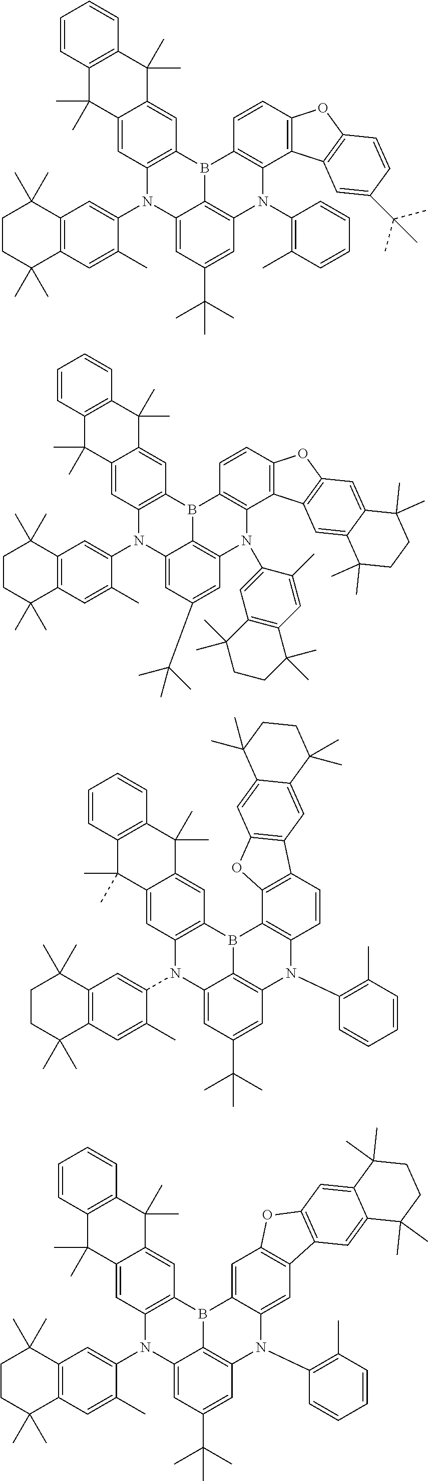

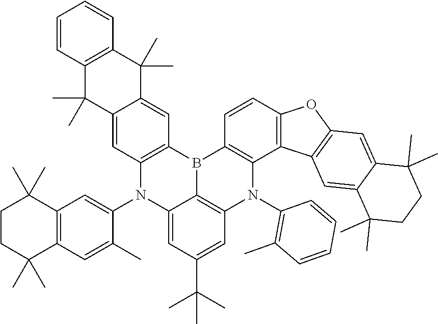 [SMILES: Cc1cc2c(cc1N1c3cc4c(cc3B3c5ccc6oc7cc8c(cc7c6c5N(c5ccccc5C)c5cc(C(C)(C)C)cc1c53)C(C)(C)CCC8(C)C)C(C)(C)c1ccccc1C4(C)C)C(C)(C)CCC2(C)C]

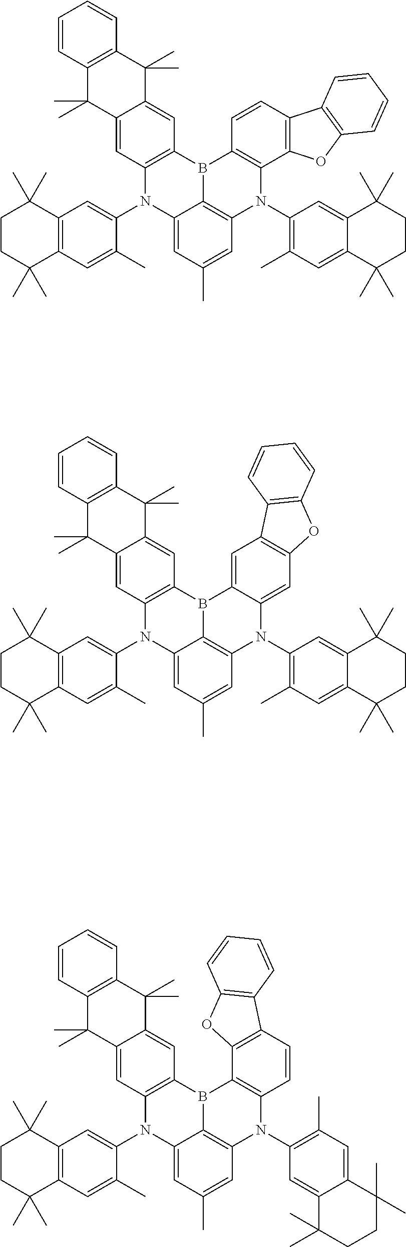 [SMILES: Cc1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1cc4oc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1ccc4c(oc5ccccc54)c1B3c1cc3c(cc1N2c1cc2c(cc1C)C(C)(C)CCC2(C)C)C(C)(C)c1ccccc1C3(C)C]

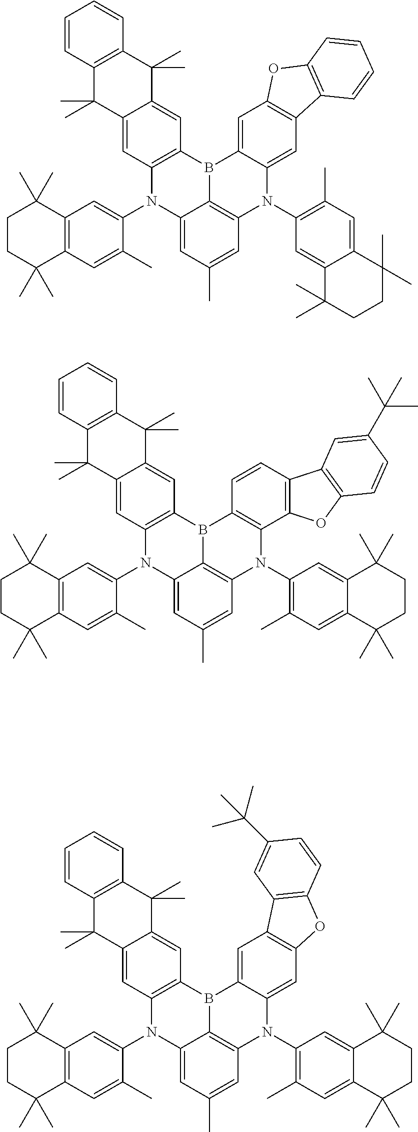 [SMILES: Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1ccccc14 ; Cc1cc2c3c(c1)N(c1cc4c(cc1C)C(C)(C)CCC4(C)C)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C]

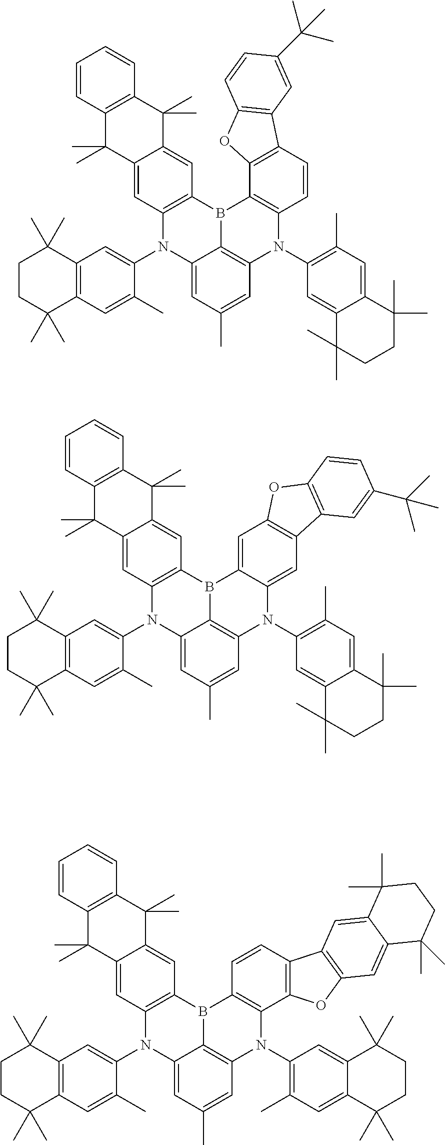 [SMILES: Cc1cc2c3c(c1)N(c1cc4c(cc1C)C(C)(C)CCC4(C)C)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

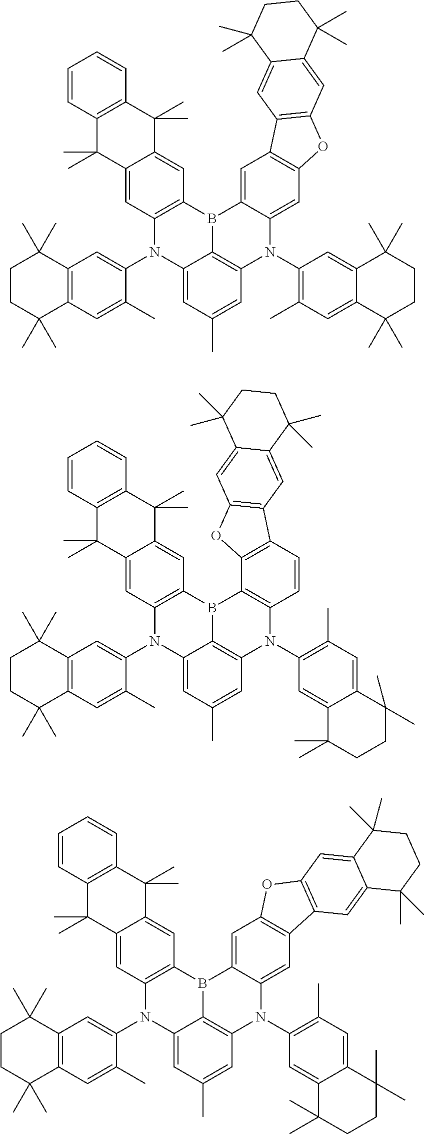

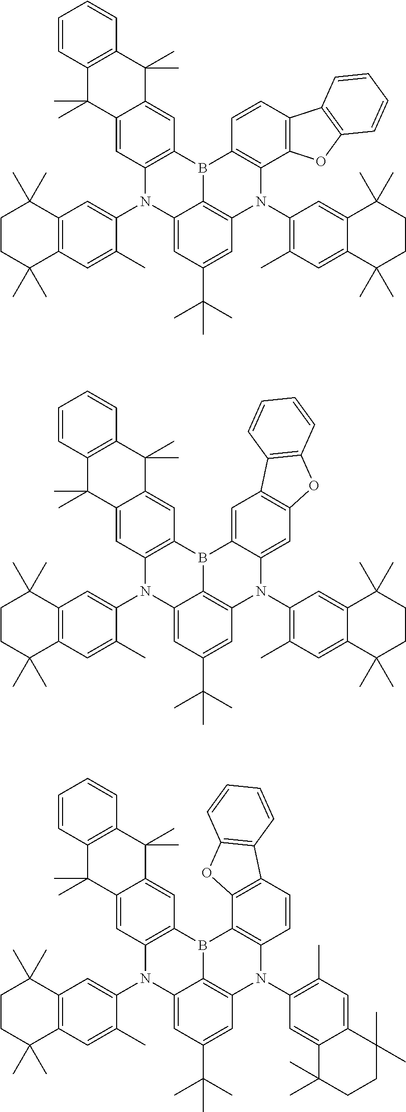 [SMILES: Cc1cc2c(cc1N1c3cc4c(cc3B3c5ccc6c(oc7ccccc76)c5N(c5cc6c(cc5C)C(C)(C)CCC6(C)C)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C(C)(C)C)cc1c53)oc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(oc6ccccc65)c13)C(C)(C)c1ccccc1C4(C)C)C(C)(C)CCC2(C)C]

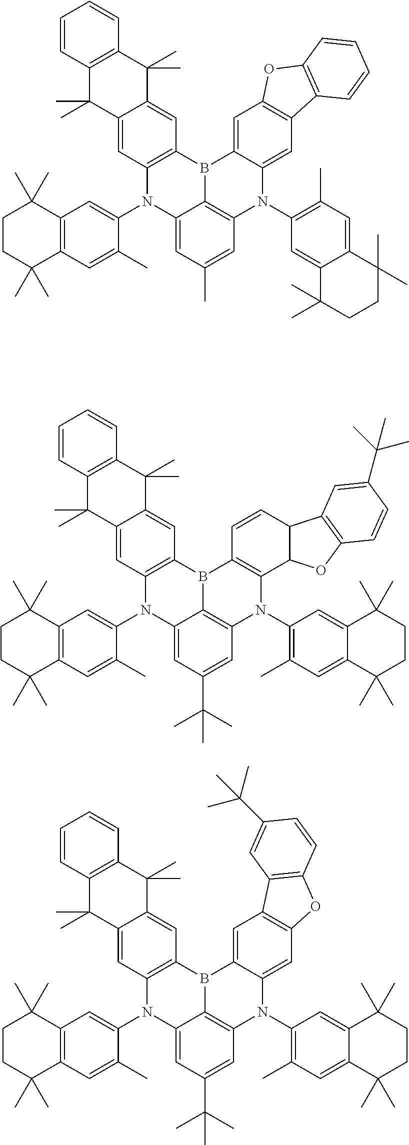

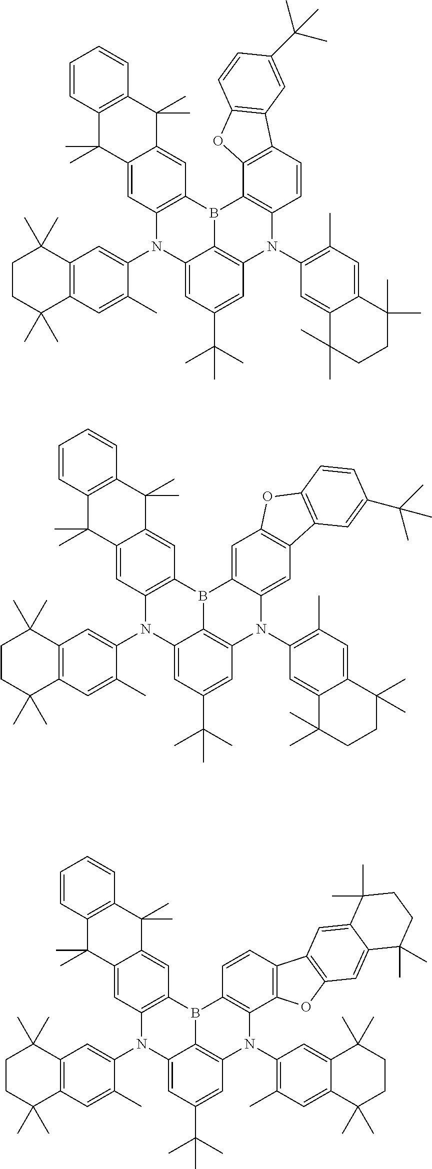 [SMILES: Cc1cc2c(cc1N1c3cc4c(cc3B3c5c1cc(C(C)(C)C)cc5N(c1cc5c(cc1C)C(C)(C)CCC5(C)C)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6oc7ccc(C(C)(C)C)cc7c6cc5N(c5cc6c(cc5C)C(C)(C)CCC6(C)C)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5cc6c(cc5C)C(C)(C)CCC6(C)C)c5cc(C(C)(C)C)cc1c53)C(C)(C)c1ccccc1C4(C)C)C(C)(C)CCC2(C)C]

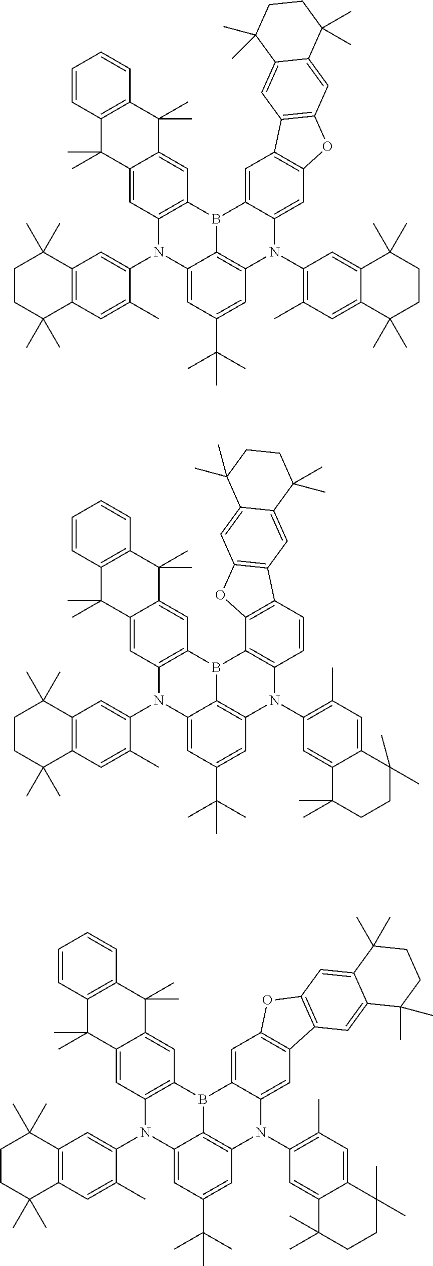 [SMILES: Cc1cc2c(cc1N1c3cc4c(cc3B3c5cc6c(cc5N(c5cc7c(cc5C)C(C)(C)CCC7(C)C)c5cc(C(C)(C)C)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5cc6c(cc5C)C(C)(C)CCC6(C)C)c5cc(C(C)(C)C)cc1c53)C(C)(C)CCC8(C)C)C(C)(C)c1ccccc1C4(C)C)C(C)(C)CCC2(C)C]

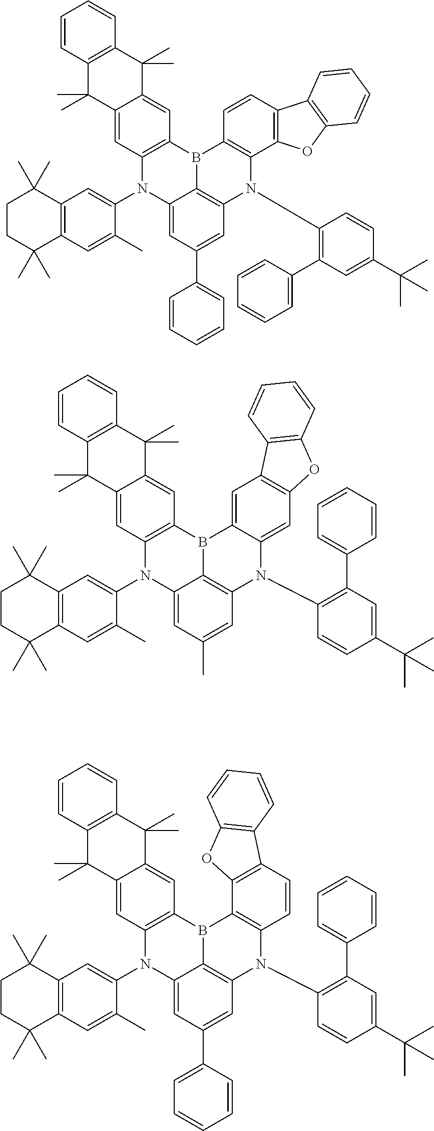 [SMILES: Cc1cc2c(cc1N1c3cc4c(cc3B3c5ccc6c(oc7ccccc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c3c(c1)N(c1ccc(C(C)(C)C)cc1-c1ccccc1)c1cc4oc5ccccc5c4cc1B3c1cc3c(cc1N2c1cc2c(cc1C)C(C)(C)CCC2(C)C)C(C)(C)c1ccccc1C3(C)C ; Cc1cc2c(cc1N1c3cc4c(cc3B3c5c1cc(-c1ccccc1)cc5N(c1ccc(C(C)(C)C)cc1-c1ccccc1)c1ccc5c(oc6ccccc65)c13)C(C)(C)c1ccccc1C4(C)C)C(C)(C)CCC2(C)C]

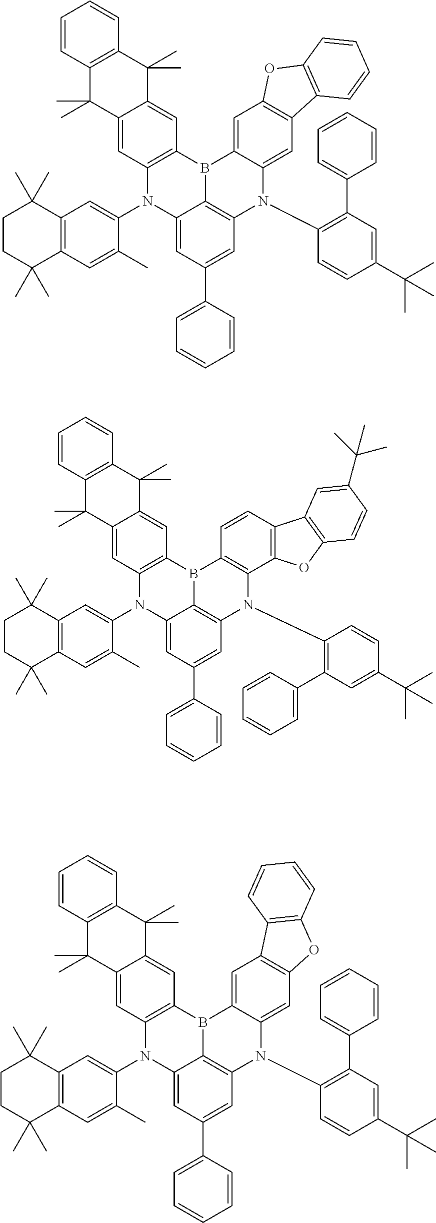 [SMILES: Cc1cc2c(cc1N1c3cc4c(cc3B3c5cc6oc7ccccc7c6cc5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)oc1ccccc16)C(C)(C)c1ccccc1C4(C)C)C(C)(C)CCC2(C)C]

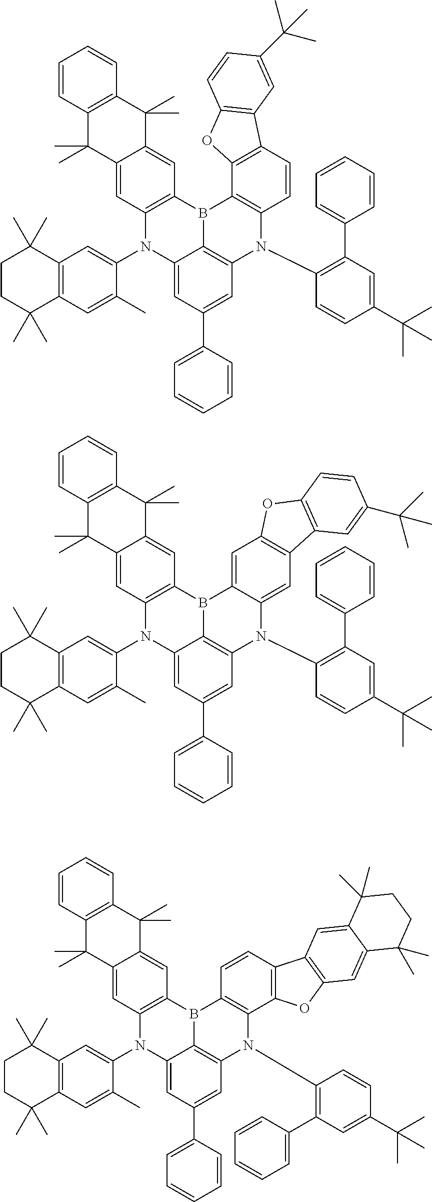 [SMILES: Cc1cc2c(cc1N1c3cc4c(cc3B3c5c1cc(-c1ccccc1)cc5N(c1ccc(C(C)(C)C)cc1-c1ccccc1)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6oc7ccc(C(C)(C)C)cc7c6cc5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccc(C(C)(C)C)cc5-c5ccccc5)c5cc(-c6ccccc6)cc1c53)C(C)(C)c1ccccc1C4(C)C)C(C)(C)CCC2(C)C]

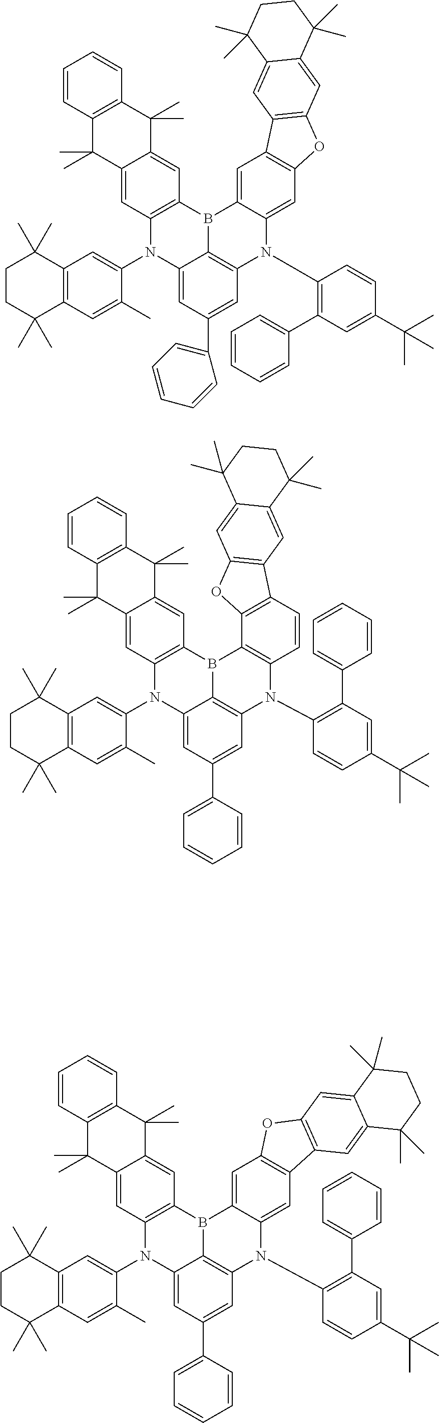

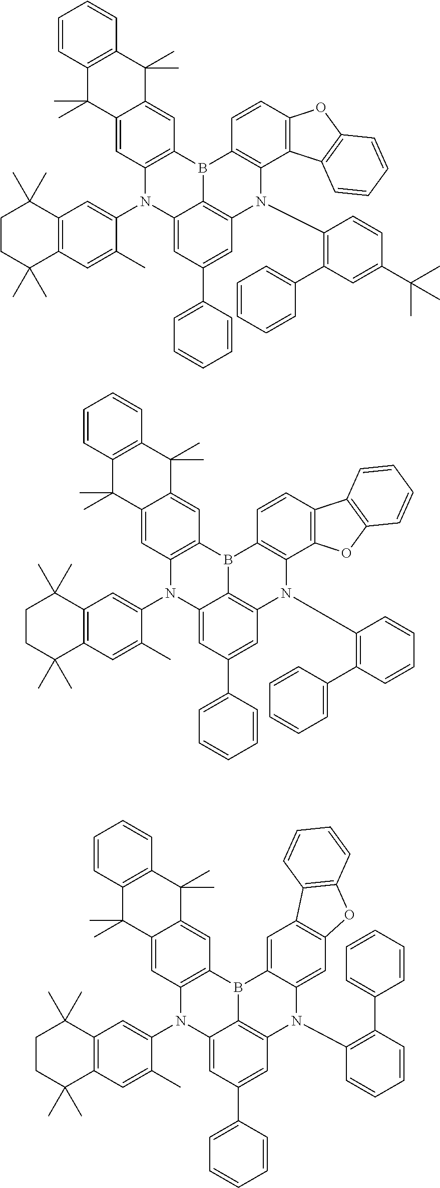 [SMILES: Cc1cc2c(cc1N1c3cc4c(cc3B3c5ccc6oc7ccccc7c6c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)oc1ccccc16)C(C)(C)c1ccccc1C4(C)C)C(C)(C)CCC2(C)C]

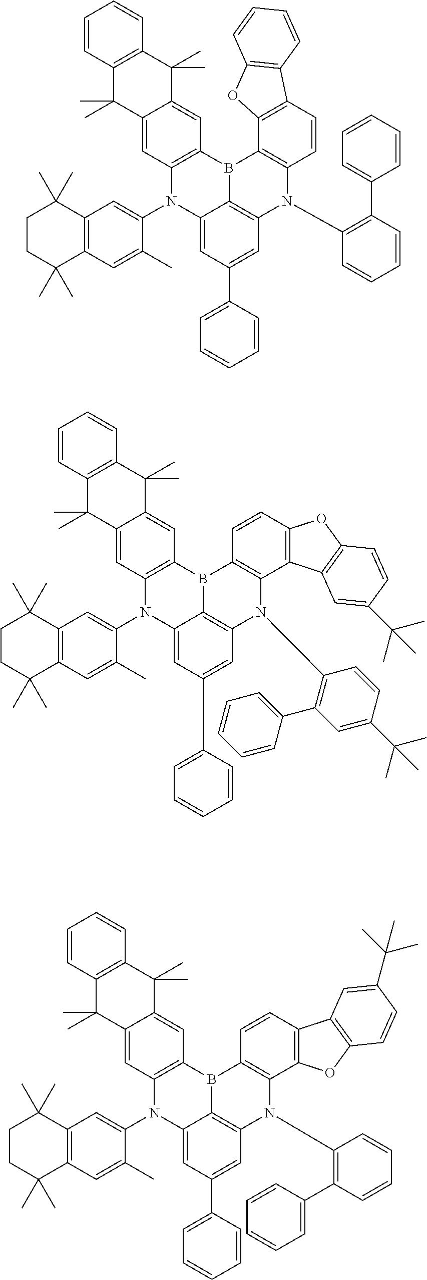 [SMILES: Cc1cc2c(cc1N1c3cc4c(cc3B3c5c1cc(-c1ccccc1)cc5N(c1ccccc1-c1ccccc1)c1ccc5c(oc6ccccc65)c13)C(C)(C)c1ccccc1C4(C)C)C(C)(C)CCC2(C)C ; Cc1cc2c(cc1N1c3cc4c(cc3B3c5ccc6oc7ccc(C(C)(C)C)cc7c6c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5-c5ccccc5)c5cc(-c6ccccc6)cc1c53)C(C)(C)c1ccccc1C4(C)C)C(C)(C)CCC2(C)C]

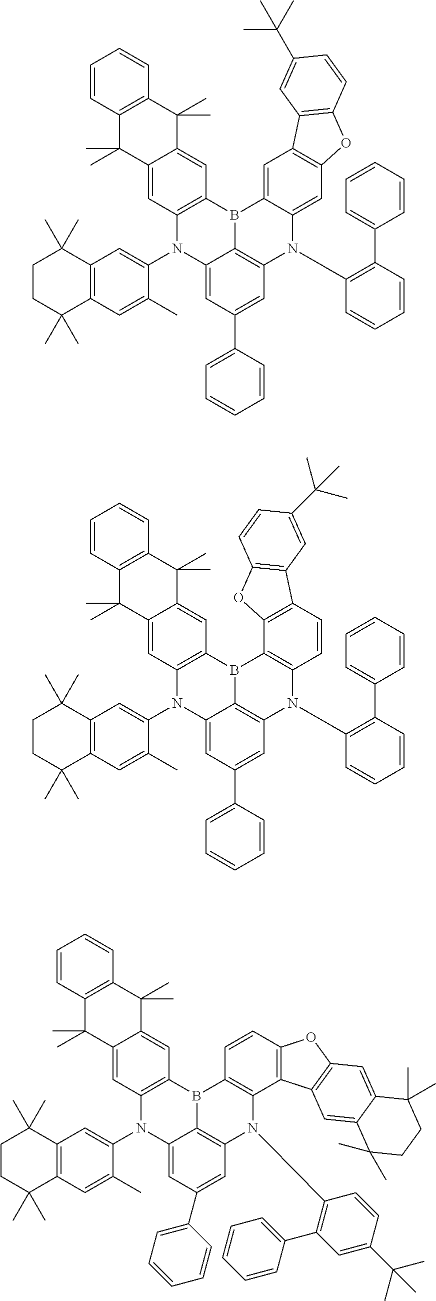 [SMILES: Cc1cc2c(cc1N1c3cc4c(cc3B3c5cc6c(cc5N(c5ccccc5-c5ccccc5)c5cc(-c7ccccc7)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccc(C(C)(C)C)cc5-c5ccccc5)c5cc(-c6ccccc6)cc1c53)C(C)(C)CCC8(C)C)C(C)(C)c1ccccc1C4(C)C)C(C)(C)CCC2(C)C]

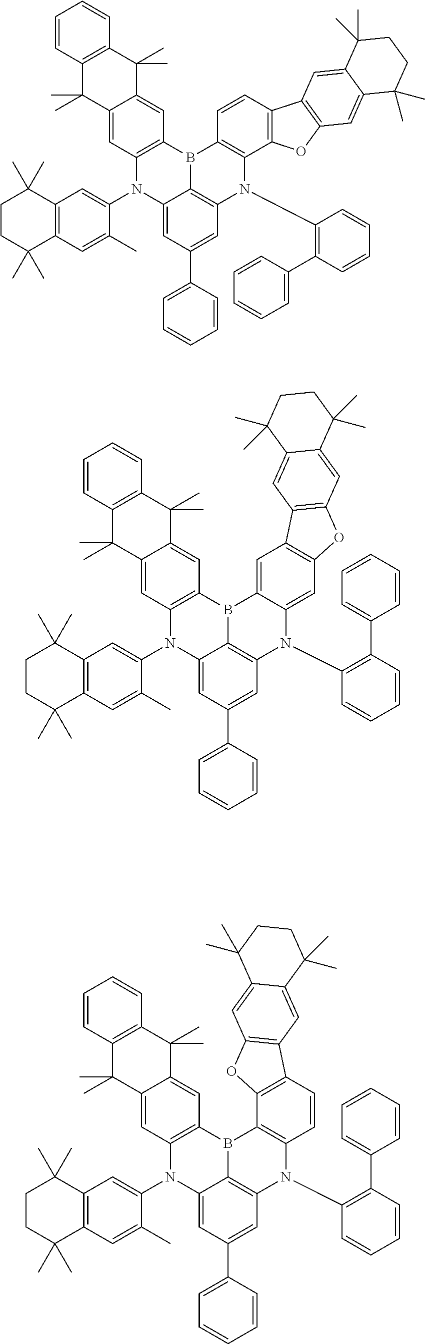 [SMILES: Cc1cc2c(cc1N1c3cc4c(cc3B3c5ccc6c(oc7cc8c(cc76)C(C)(C)CCC8(C)C)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(oc6cc7c(cc65)C(C)(C)CCC7(C)C)c13)C(C)(C)c1ccccc1C4(C)C)C(C)(C)CCC2(C)C]

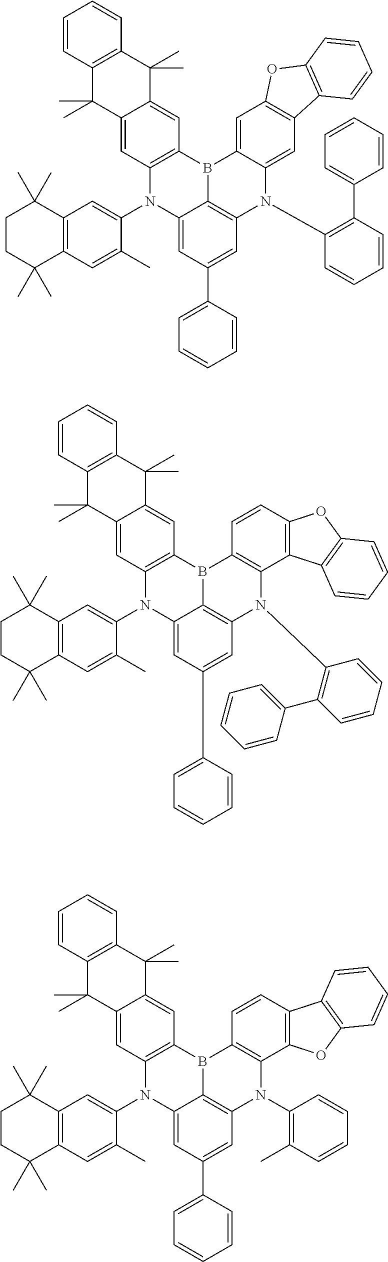 [SMILES: Cc1cc2c(cc1N1c3cc4c(cc3B3c5cc6oc7ccccc7c6cc5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5C)c5cc(-c6ccccc6)cc1c53)C(C)(C)c1ccccc1C4(C)C)C(C)(C)CCC2(C)C]

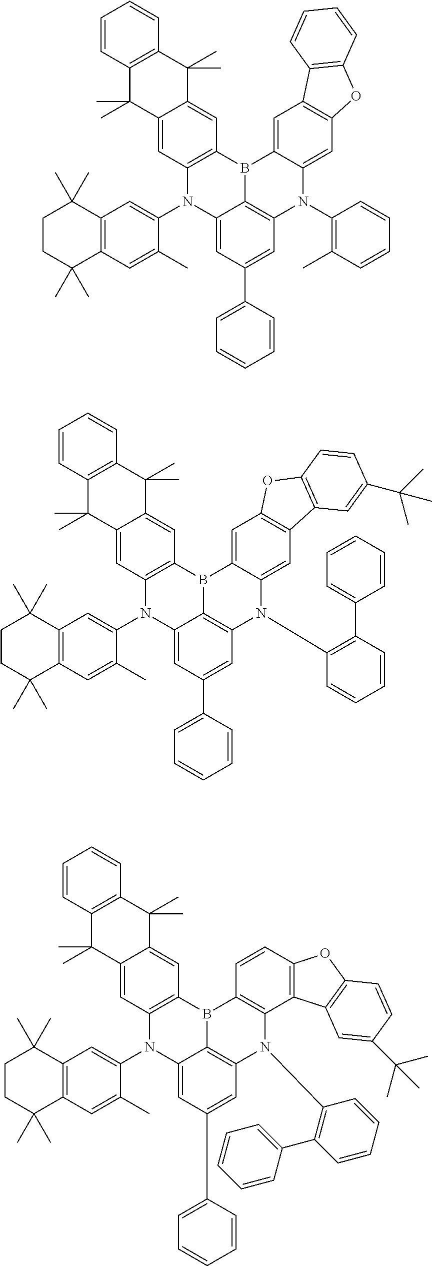 [SMILES: Cc1ccccc1N1c2cc3oc4ccccc4c3cc2B2c3cc4c(cc3N(c3cc5c(cc3C)C(C)(C)CCC5(C)C)c3cc(-c5ccccc5)cc1c32)C(C)(C)c1ccccc1C4(C)C ; Cc1cc2c(cc1N1c3cc4c(cc3B3c5cc6oc7ccc(C(C)(C)C)cc7c6cc5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6oc7ccc(C(C)(C)C)cc7c6c5N(c5ccccc5-c5ccccc5)c5cc(-c6ccccc6)cc1c53)C(C)(C)c1ccccc1C4(C)C)C(C)(C)CCC2(C)C]

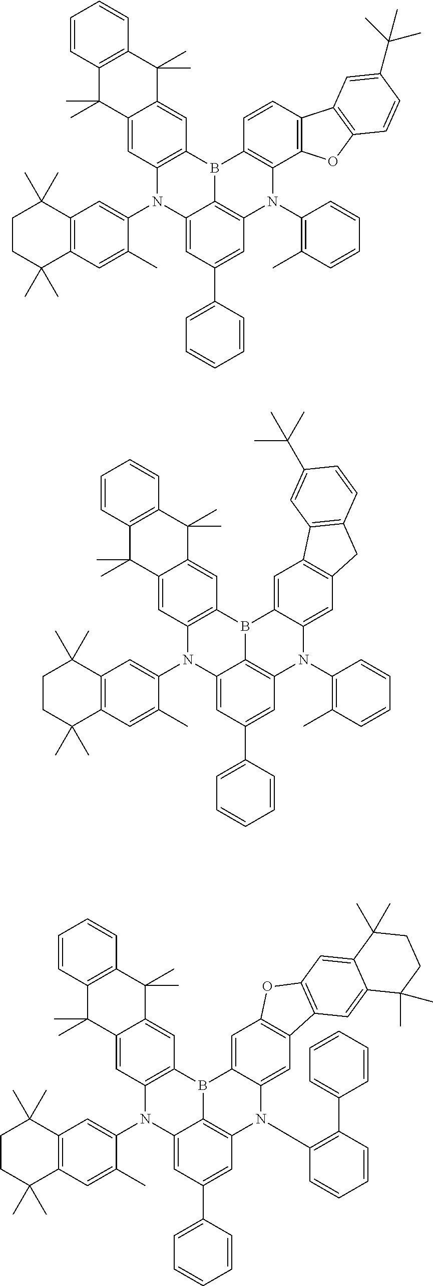 [SMILES: Cc1cc2c(cc1N1c3cc4c(cc3B3c5ccc6c(oc7ccc(C(C)(C)C)cc76)c5N(c5ccccc5C)c5cc(-c6ccccc6)cc1c53)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)-c1cc(C(C)(C)C)ccc1C3 ; Cc1cc2c(cc1N1c3cc4c(cc3B3c5cc6oc7cc8c(cc7c6cc5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C]

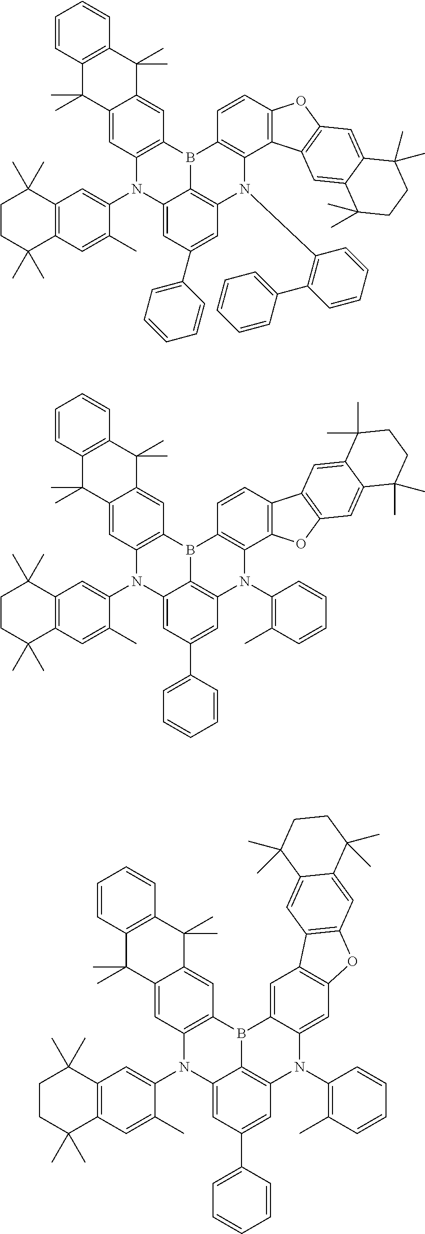 [SMILES: Cc1cc2c(cc1N1c3cc4c(cc3B3c5ccc6oc7cc8c(cc7c6c5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5C)c5cc(-c6ccccc6)cc1c53)C(C)(C)c1ccccc1C4(C)C)C(C)(C)CCC2(C)C ; Cc1ccccc1N1c2cc3oc4cc5c(cc4c3cc2B2c3cc4c(cc3N(c3cc6c(cc3C)C(C)(C)CCC6(C)C)c3cc(-c6ccccc6)cc1c32)C(C)(C)c1ccccc1C4(C)C)C(C)(C)CCC5(C)C]

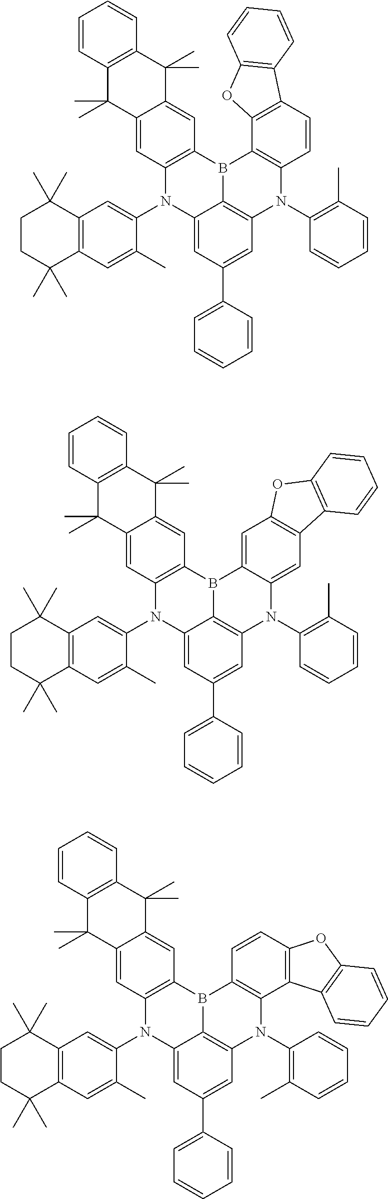 [SMILES: Cc1cc2c(cc1N1c3cc4c(cc3B3c5c1cc(-c1ccccc1)cc5N(c1ccccc1C)c1ccc5c(oc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)oc1ccccc13 ; Cc1cc2c(cc1N1c3cc4c(cc3B3c5ccc6oc7ccccc7c6c5N(c5ccccc5C)c5cc(-c6ccccc6)cc1c53)C(C)(C)c1ccccc1C4(C)C)C(C)(C)CCC2(C)C]

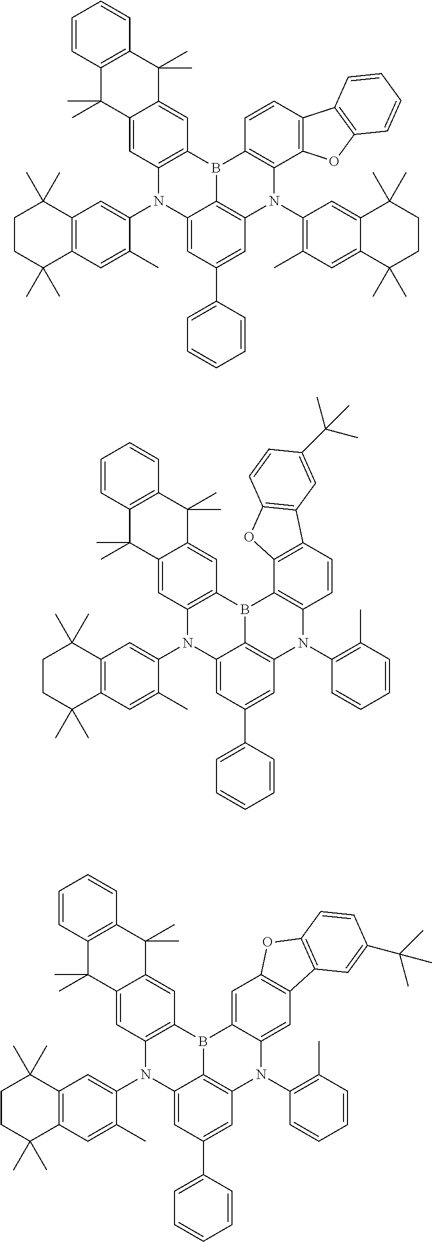 [SMILES: Cc1cc2c(cc1N1c3cc4c(cc3B3c5ccc6c(oc7ccccc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1C)c1ccc5c(oc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)oc1ccc(C(C)(C)C)cc13]

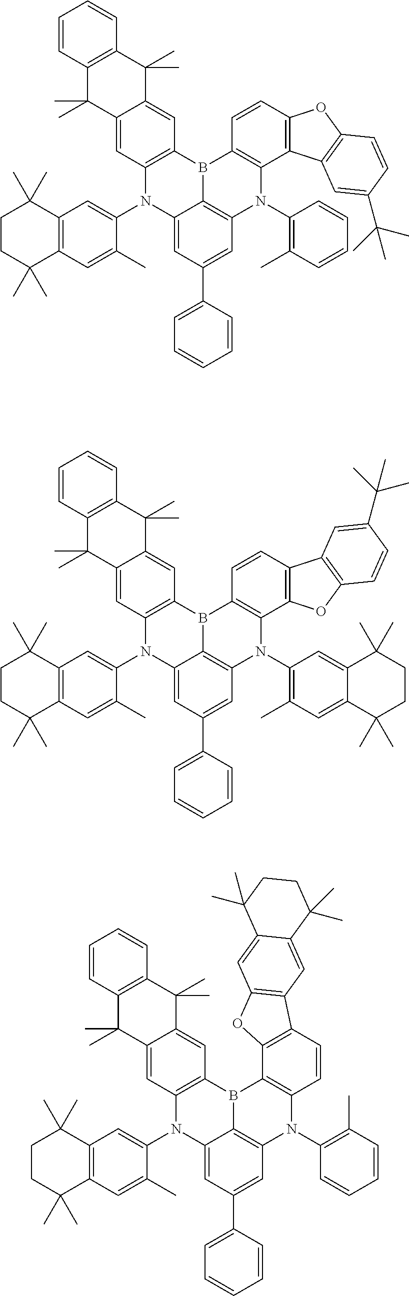 [SMILES: Cc1cc2c(cc1N1c3cc4c(cc3B3c5ccc6oc7ccc(C(C)(C)C)cc7c6c5N(c5ccccc5C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1C)c1ccc5c(oc6cc7c(cc65)C(C)(C)CCC7(C)C)c13)C(C)(C)c1ccccc1C4(C)C)C(C)(C)CCC2(C)C]

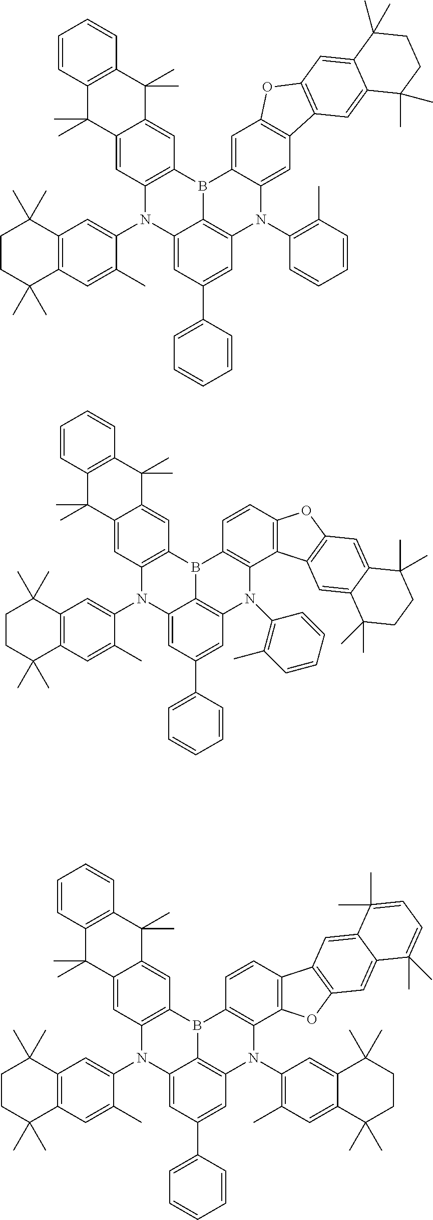

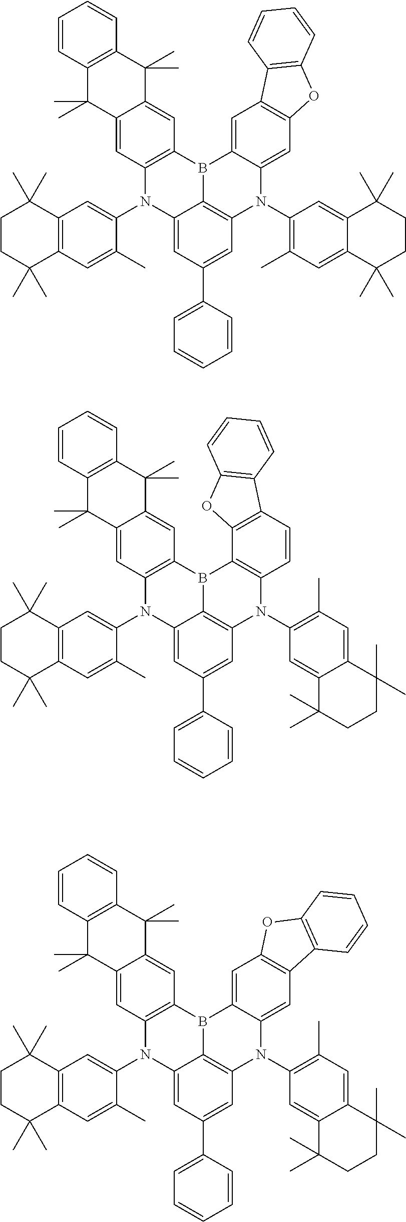 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)oc1ccccc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C]

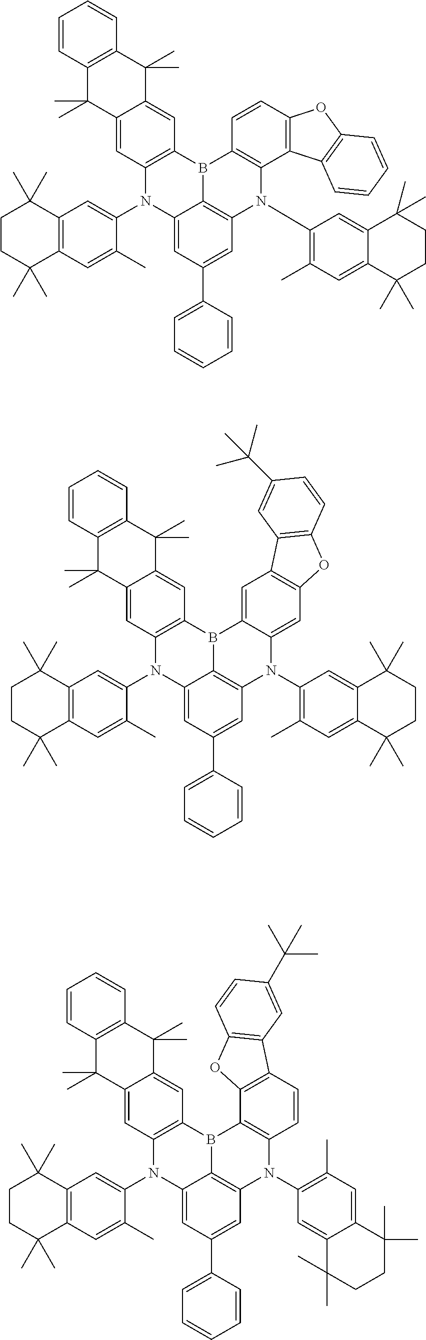 [SMILES: Cc1cc2c(cc1N1c3cc4c(cc3B3c5ccc6oc7ccccc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)oc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(oc6ccc(C(C)(C)C)cc65)c13)C(C)(C)c1ccccc1C4(C)C)C(C)(C)CCC2(C)C]

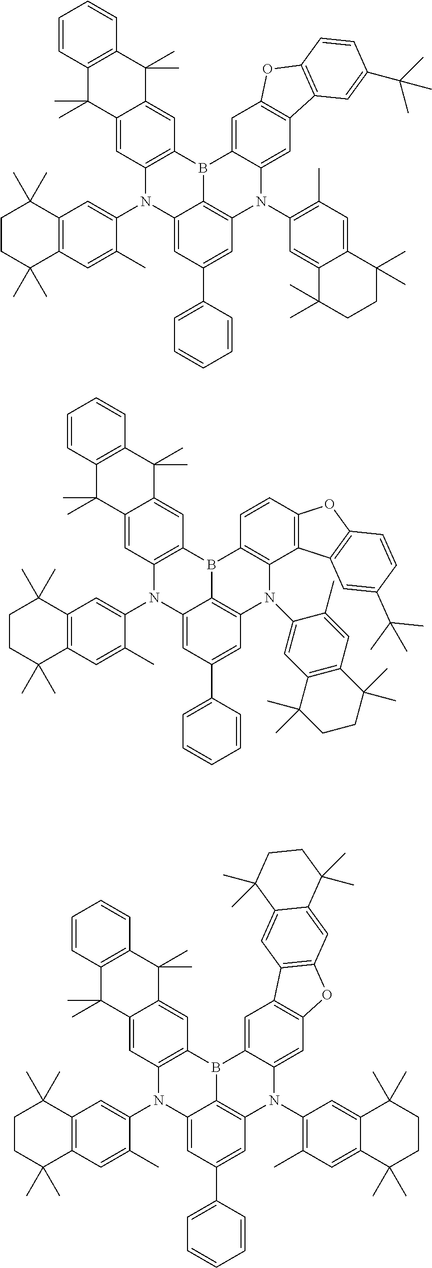 [SMILES: Cc1cc2c(cc1N1c3cc4c(cc3B3c5cc6oc7ccc(C(C)(C)C)cc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6oc7ccc(C(C)(C)C)cc7c6c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)oc1cc3c(cc16)C(C)(C)CCC3(C)C)C(C)(C)c1ccccc1C4(C)C)C(C)(C)CCC2(C)C]

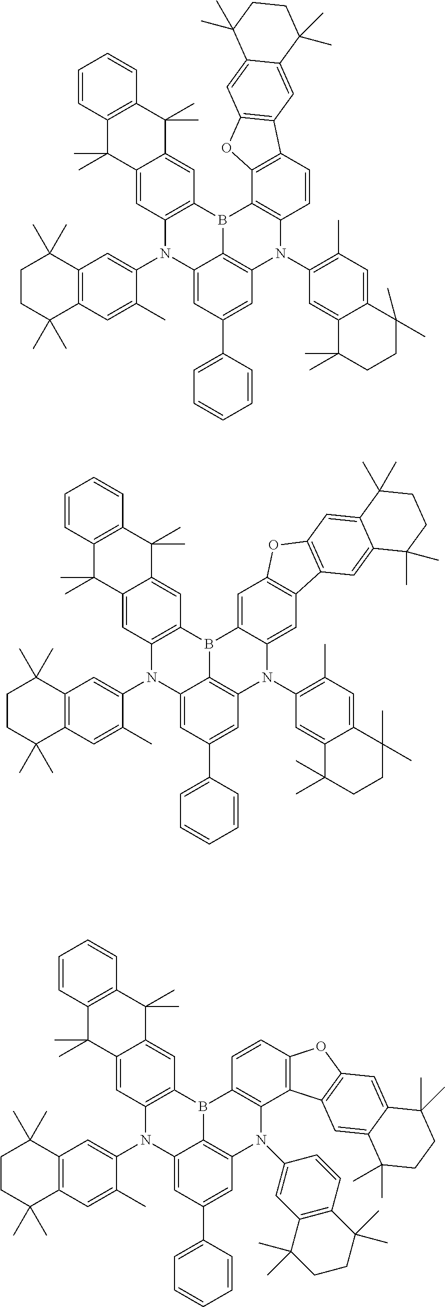 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccc6c(c5)C(C)(C)CCC6(C)C)c5cc(-c6ccccc6)cc1c53)C(C)(C)CCC8(C)C)C(C)(C)c1ccccc1C4(C)C)C(C)(C)CCC2(C)C]

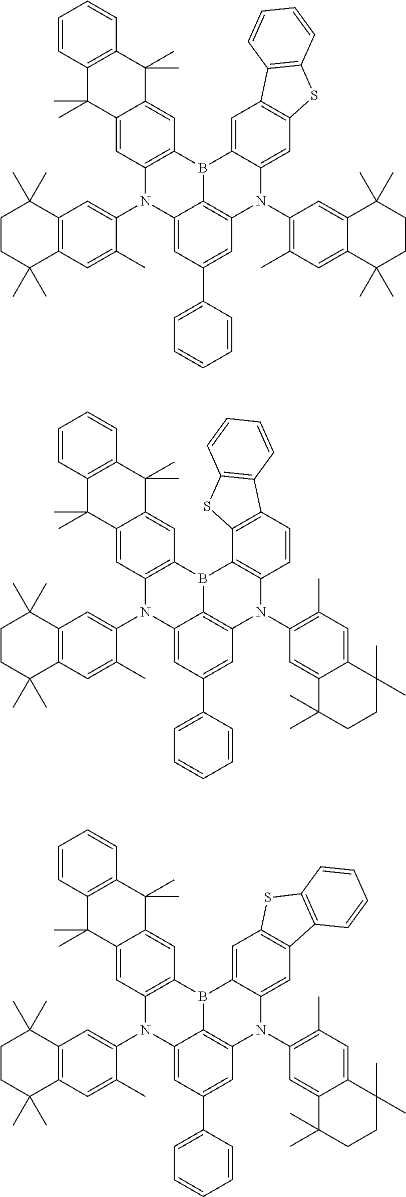 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)sc1ccccc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(sc6ccccc65)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(-c6ccccc6)cc1c53)C(C)(C)c1ccccc1C4(C)C)C(C)(C)CCC2(C)C]

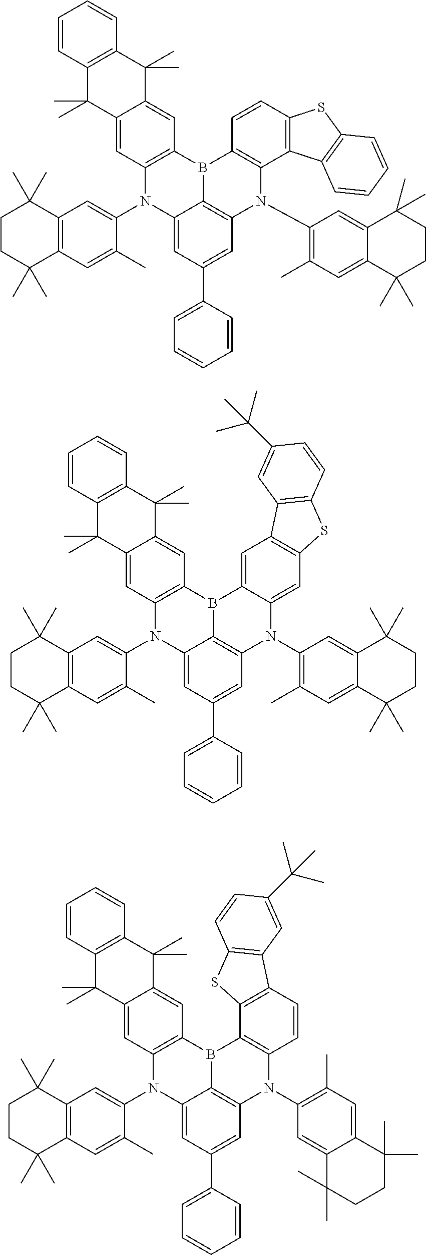

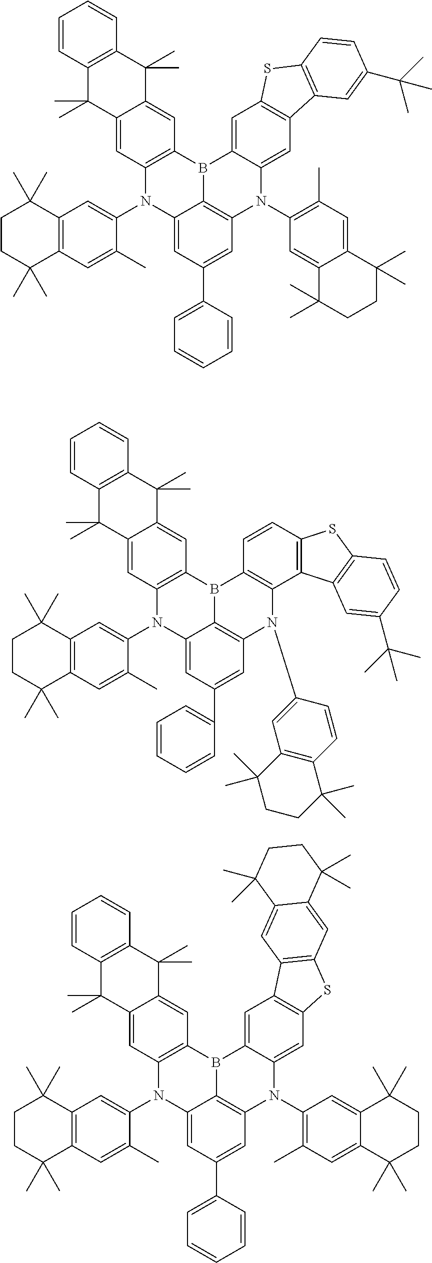

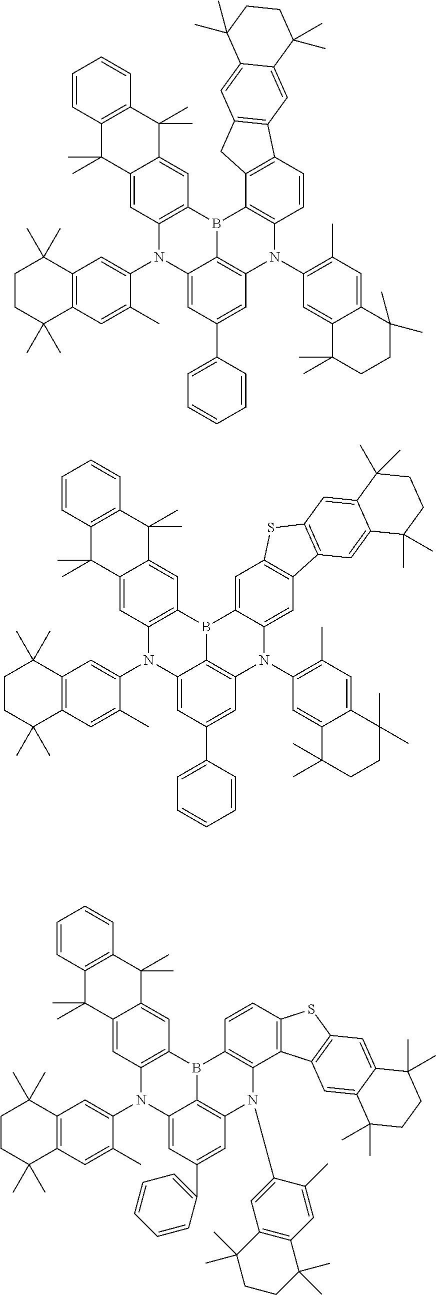 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(c13)Cc1cc3c(cc1-5)C(C)(C)CCC3(C)C)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5cc6c(cc5C)C(C)(C)CCC6(C)C)c5cc(-c6ccccc6)cc1c53)C(C)(C)CCC8(C)C)C(C)(C)c1ccccc1C4(C)C)C(C)(C)CCC2(C)C]

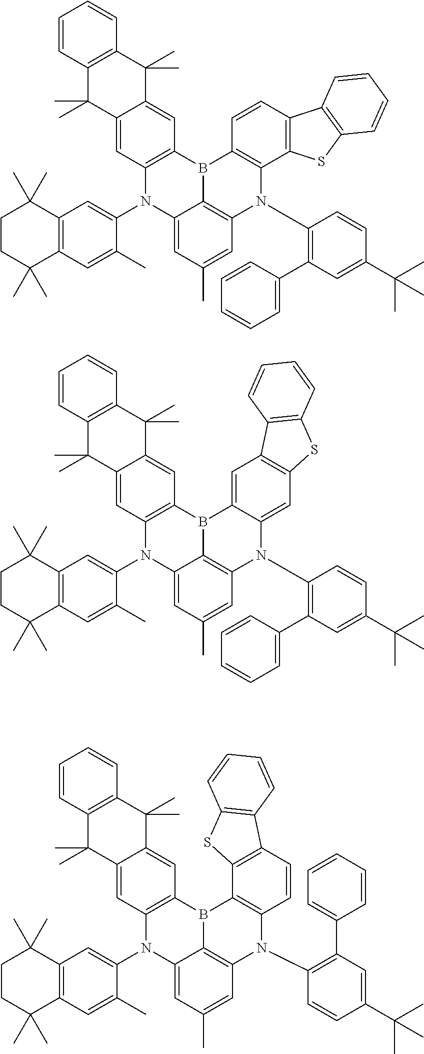

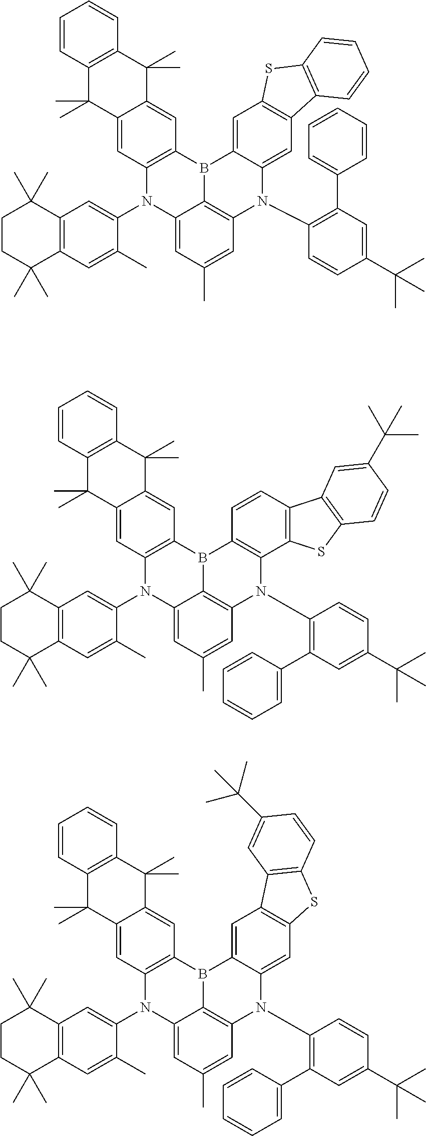

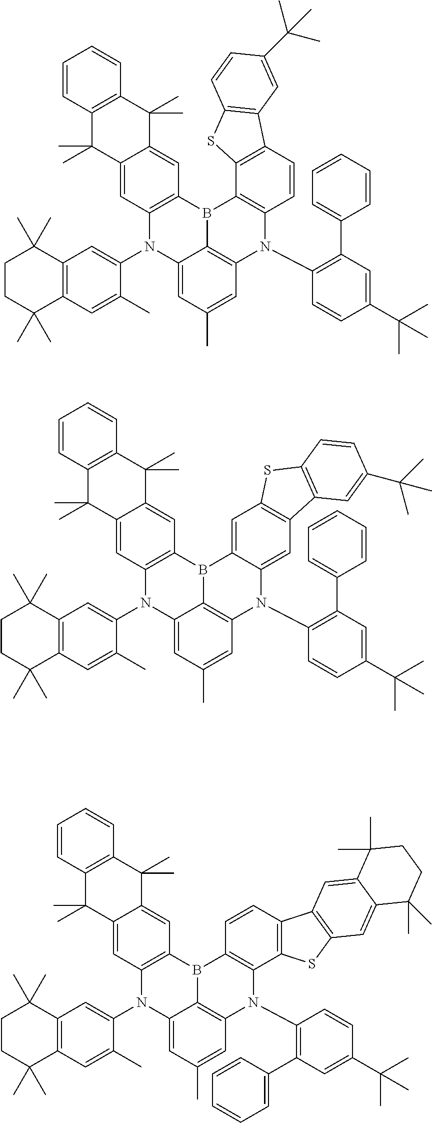 [SMILES: Cc1cc2c3c(c1)N(c1ccc(C(C)(C)C)cc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14 ; Cc1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

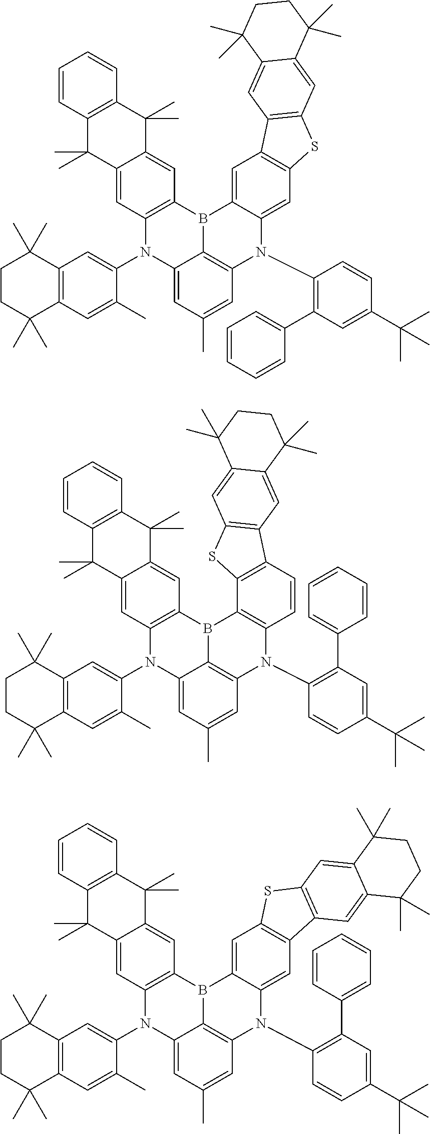

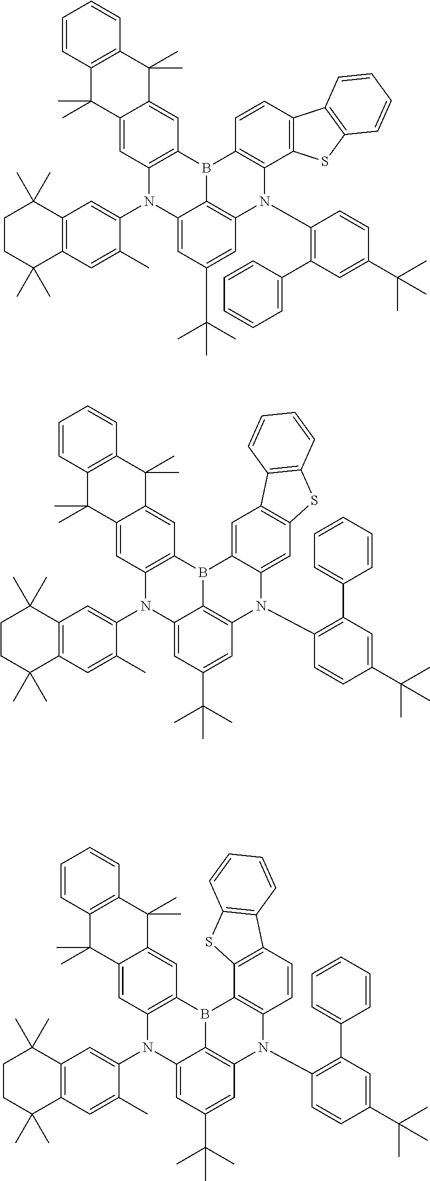 [SMILES: Cc1cc2c(cc1N1c3cc4c(cc3B3c5ccc6c(sc7ccccc76)c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)sc1ccccc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(sc6ccccc65)c13)C(C)(C)c1ccccc1C4(C)C)C(C)(C)CCC2(C)C]

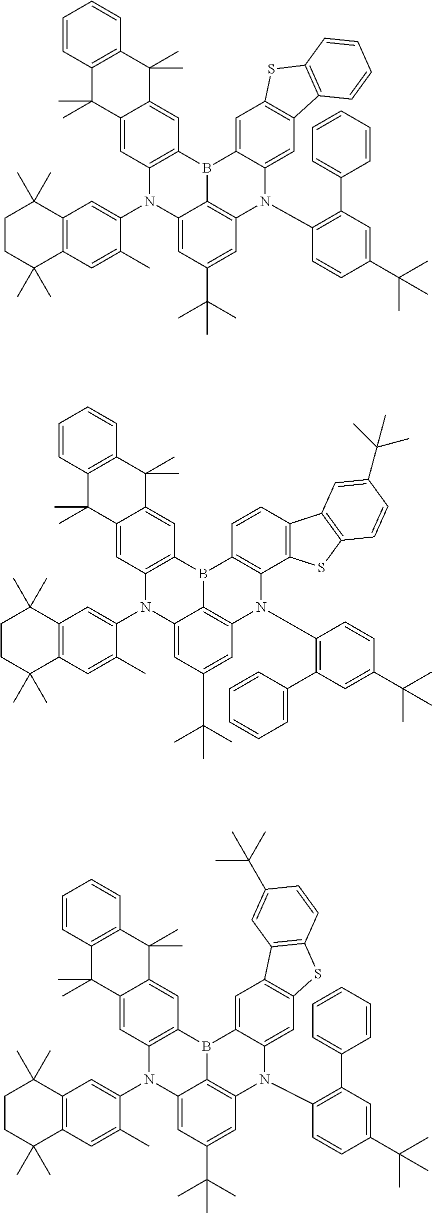 [SMILES: Cc1cc2c(cc1N1c3cc4c(cc3B3c5cc6sc7ccccc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)sc1ccc(C(C)(C)C)cc16)C(C)(C)c1ccccc1C4(C)C)C(C)(C)CCC2(C)C]

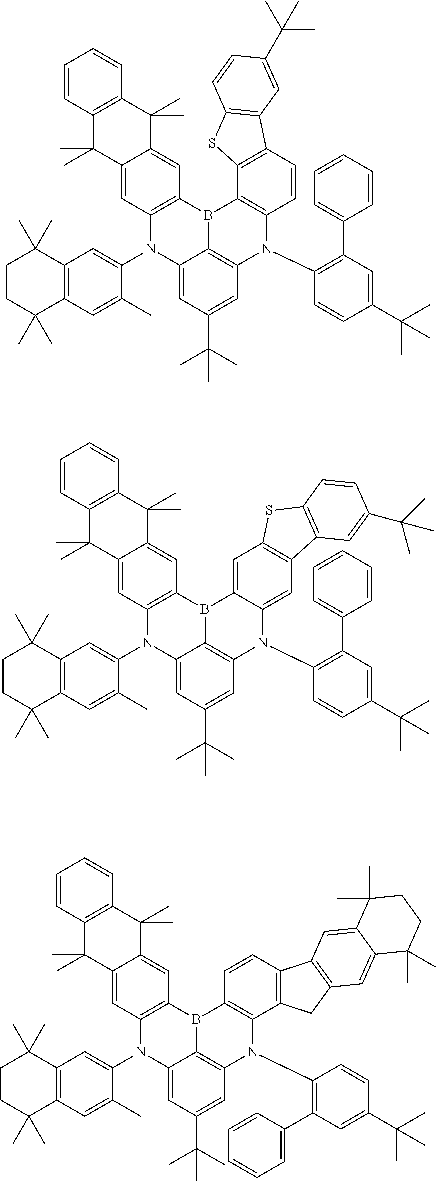 [SMILES: Cc1cc2c(cc1N1c3cc4c(cc3B3c5c1cc(C(C)(C)C)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6sc7ccc(C(C)(C)C)cc7c6cc5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(C(C)(C)C)cc1c53)Cc1cc3c(cc1-6)C(C)(C)CCC3(C)C)C(C)(C)c1ccccc1C4(C)C)C(C)(C)CCC2(C)C]

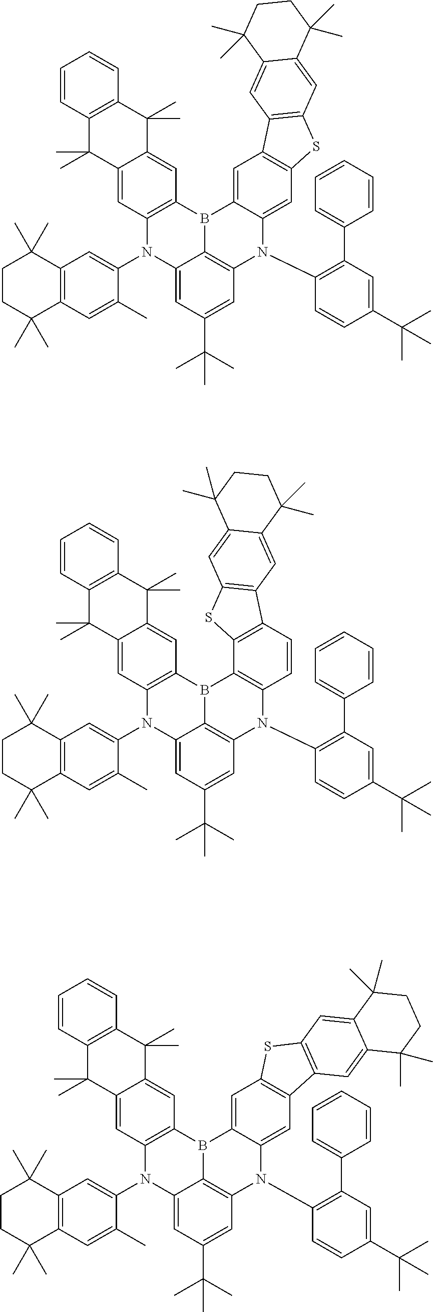 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C]

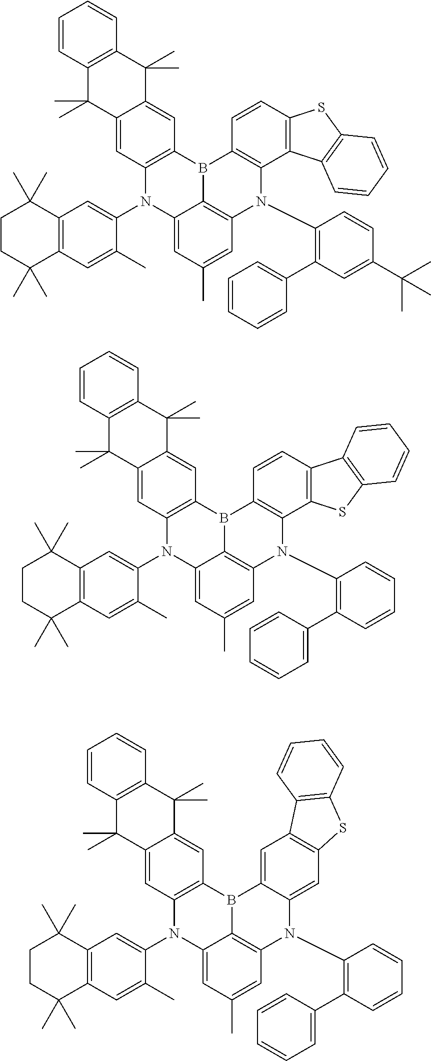 [SMILES: Cc1cc2c3c(c1)N(c1ccc(C(C)(C)C)cc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1c(ccc4c1sc1ccccc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4sc5ccccc5c4cc1B3c1cc3c(cc1N2c1cc2c(cc1C)C(C)(C)CCC2(C)C)C(C)(C)c1ccccc1C3(C)C]

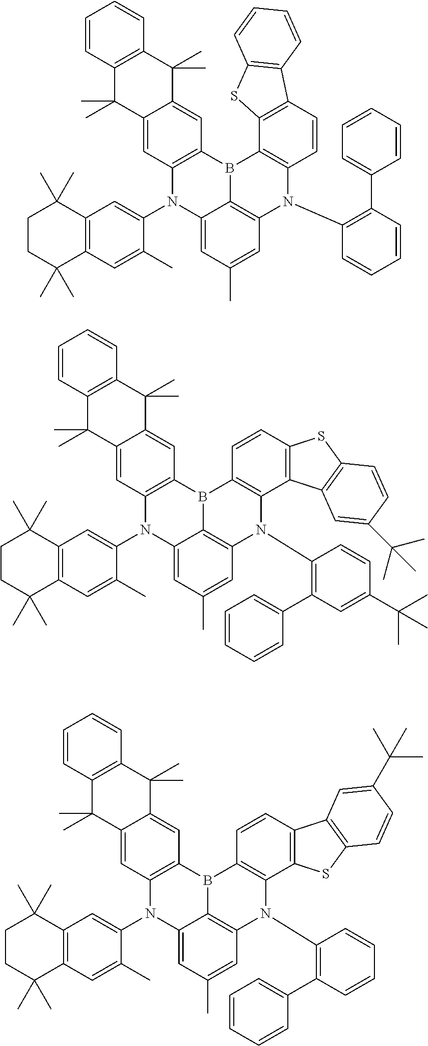

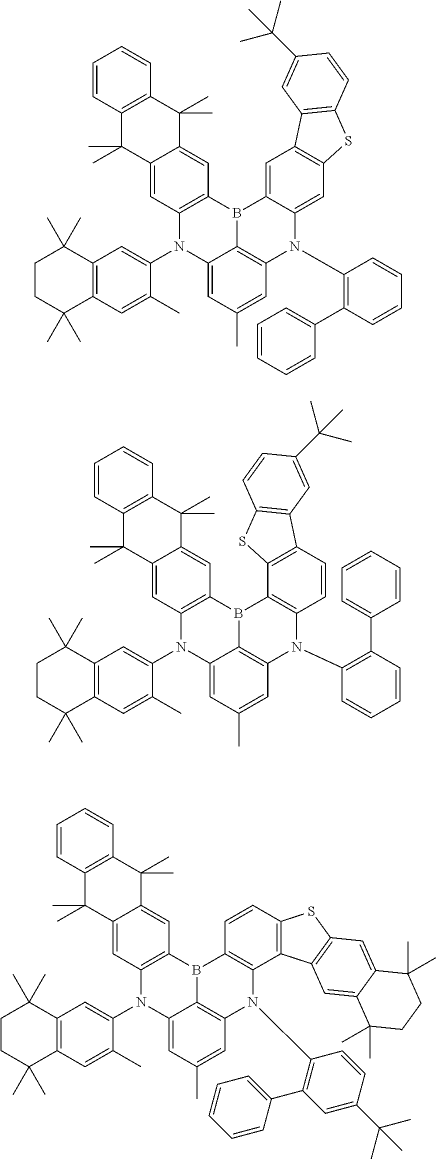

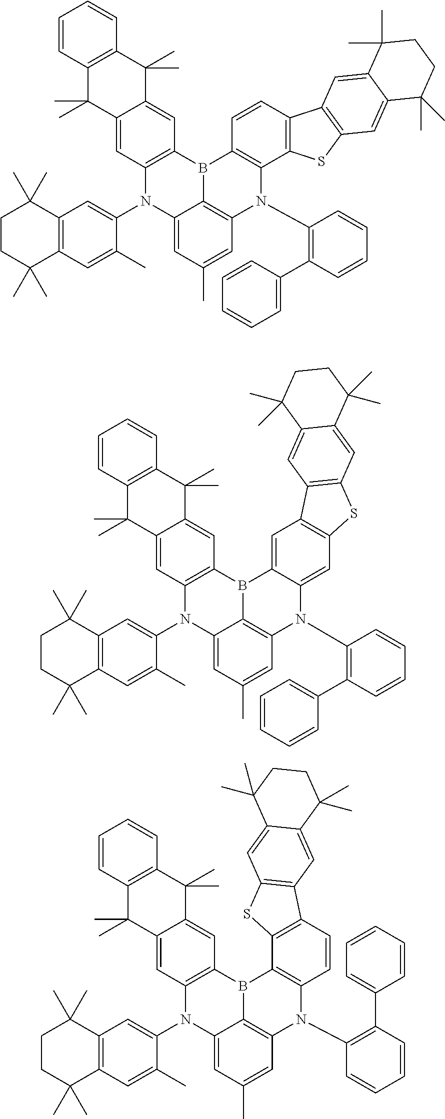

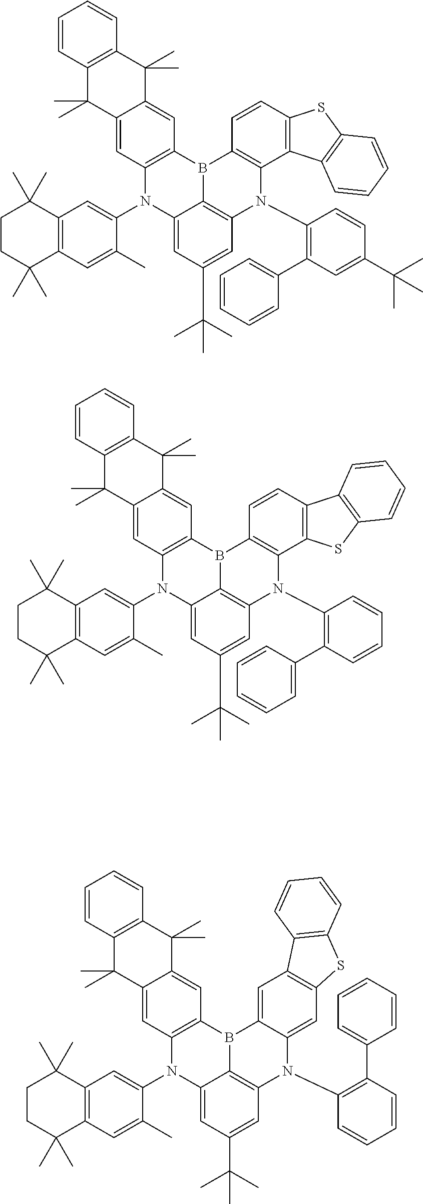 [SMILES: Cc1cc2c(cc1N1c3cc4c(cc3B3c5ccc6sc7ccccc7c6c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)sc1ccccc16)C(C)(C)c1ccccc1C4(C)C)C(C)(C)CCC2(C)C]

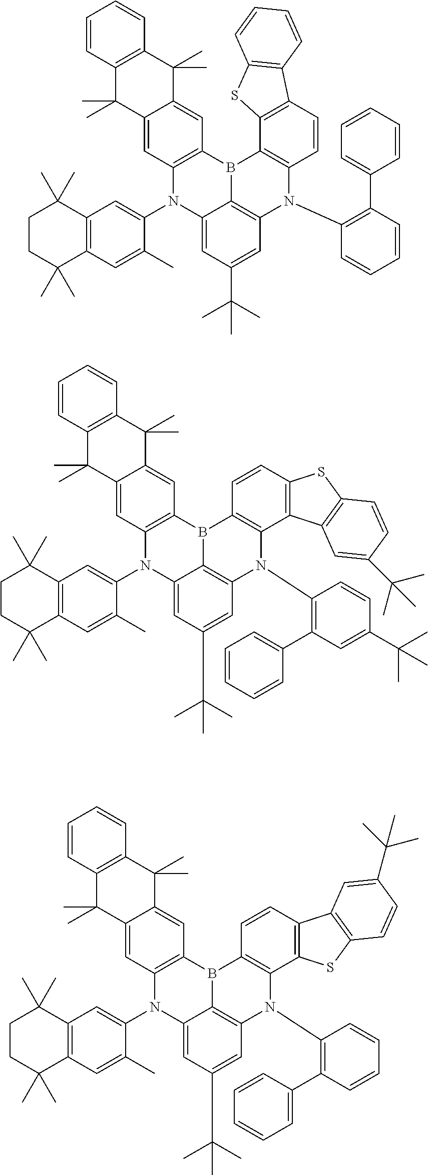 [SMILES: Cc1cc2c(cc1N1c3cc4c(cc3B3c5c1cc(C(C)(C)C)cc5N(c1ccccc1-c1ccccc1)c1ccc5c(sc6ccccc65)c13)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(C(C)(C)C)cc1c53)C(C)(C)c1ccccc1C4(C)C)C(C)(C)CCC2(C)C]

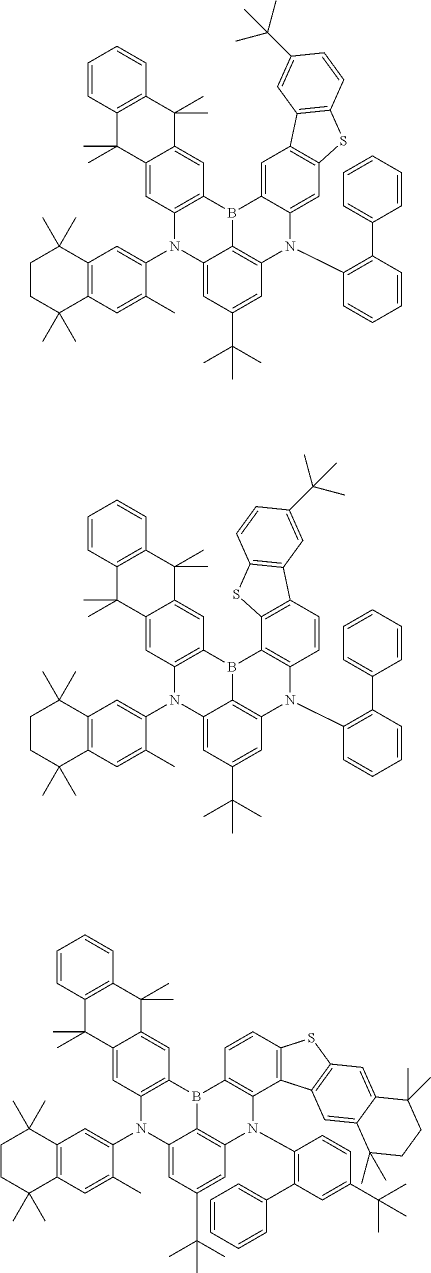 [SMILES: Cc1cc2c(cc1N1c3cc4c(cc3B3c5cc6c(cc5N(c5ccccc5-c5ccccc5)c5cc(C(C)(C)C)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(C(C)(C)C)cc1c53)C(C)(C)CCC8(C)C)C(C)(C)c1ccccc1C4(C)C)C(C)(C)CCC2(C)C]

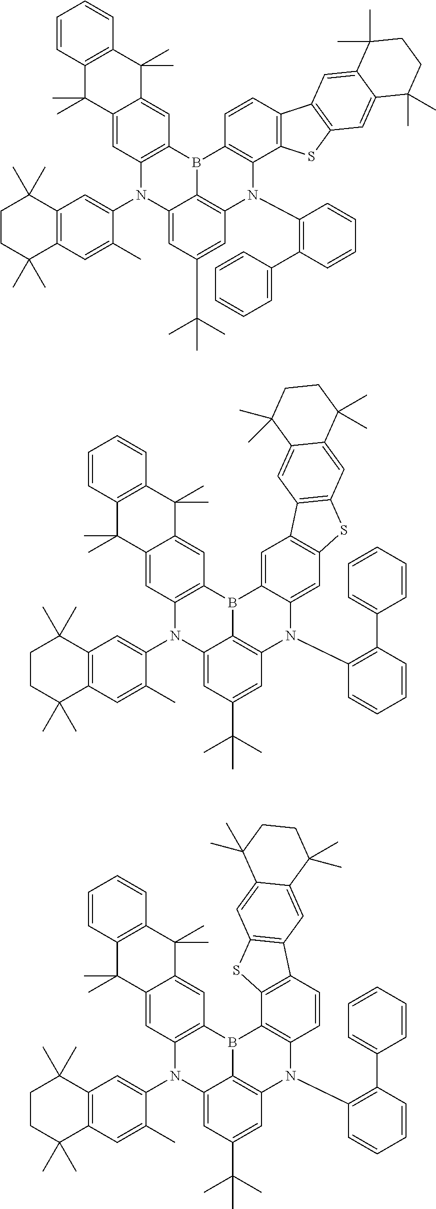 [SMILES: Cc1cc2c(cc1N1c3cc4c(cc3B3c5ccc6c(sc7cc8c(cc76)C(C)(C)CCC8(C)C)c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(sc6cc7c(cc65)C(C)(C)CCC7(C)C)c13)C(C)(C)c1ccccc1C4(C)C)C(C)(C)CCC2(C)C]

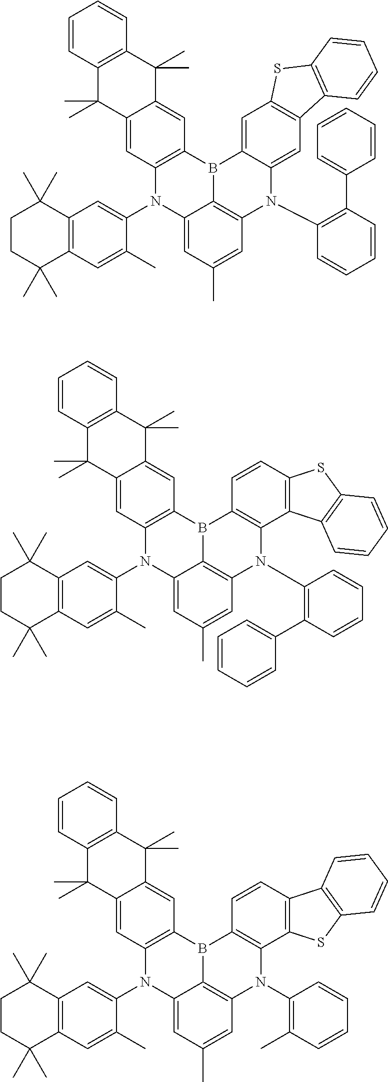 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccccc14 ; Cc1cc2c3c(c1)N(c1ccccc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)c1ccccc1C3(C)C]

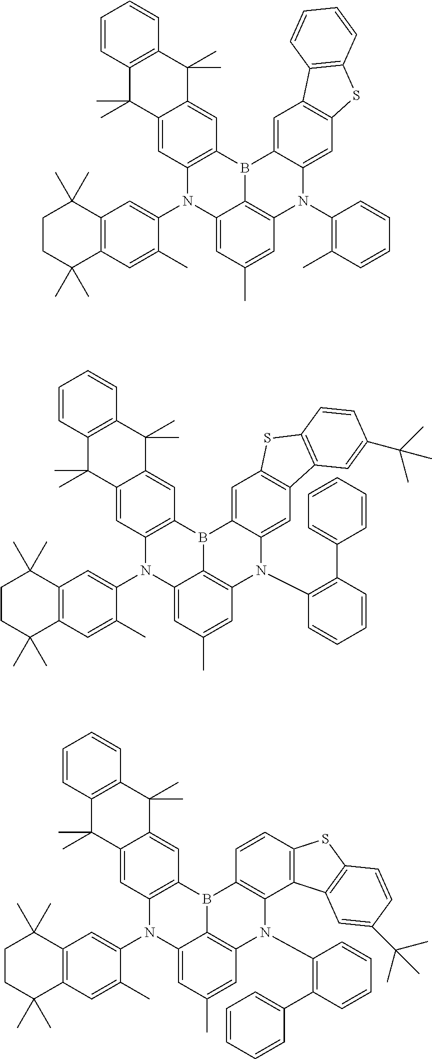 [SMILES: Cc1cc2c3c(c1)N(c1ccccc1C)c1cc4sc5ccccc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14 ; Cc1cc2c3c(c1)N(c1ccccc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)c1ccccc1C3(C)C]

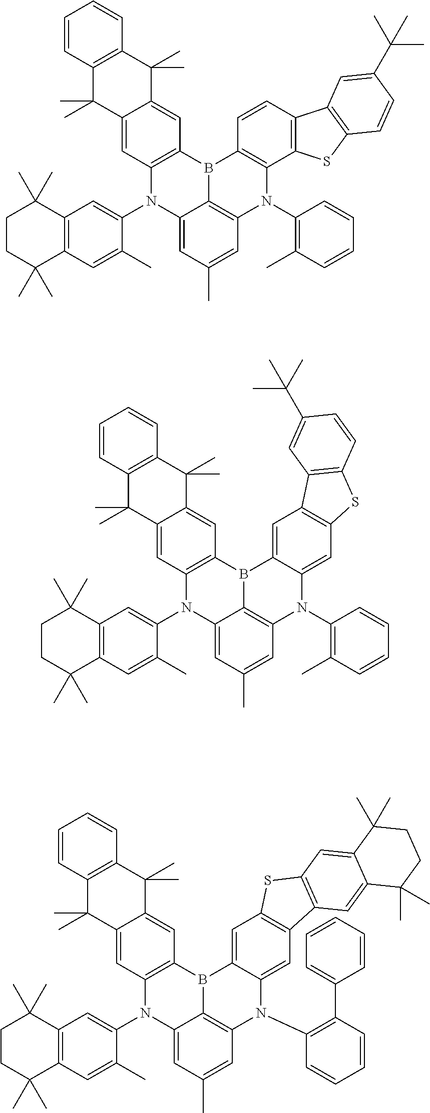 [SMILES: Cc1cc2c3c(c1)N(c1ccccc1C)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4sc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1cc2c(cc14)C(C)(C)CCC2(C)C]

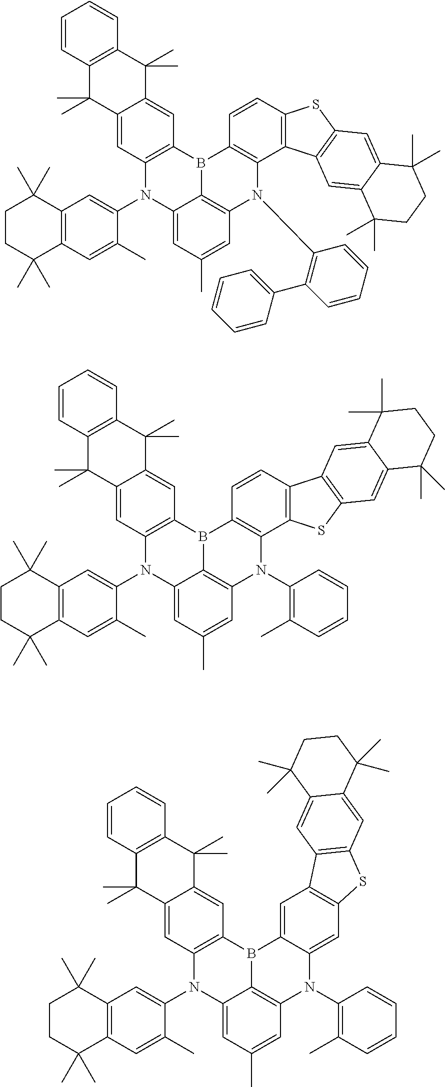 [SMILES: Cc1cc2c3c(c1)N(c1ccccc1-c1ccccc1)c1c(ccc4sc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4sc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

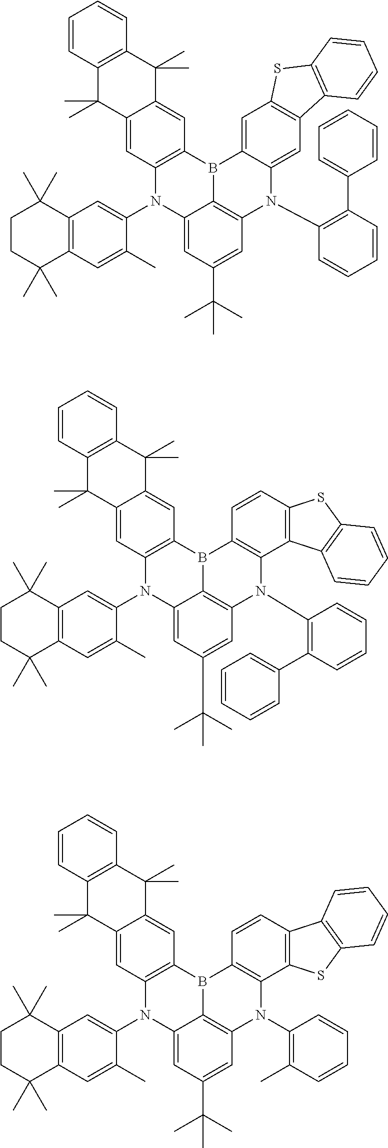 [SMILES: Cc1cc2c(cc1N1c3cc4c(cc3B3c5cc6sc7ccccc7c6cc5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5C)c5cc(C(C)(C)C)cc1c53)C(C)(C)c1ccccc1C4(C)C)C(C)(C)CCC2(C)C]

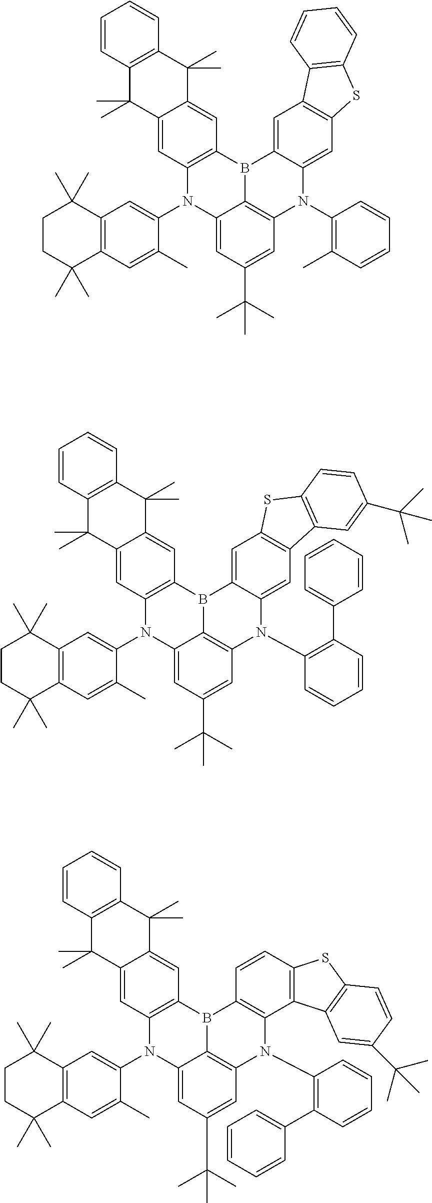 [SMILES: Cc1ccccc1N1c2cc3sc4ccccc4c3cc2B2c3cc4c(cc3N(c3cc5c(cc3C)C(C)(C)CCC5(C)C)c3cc(C(C)(C)C)cc1c32)C(C)(C)c1ccccc1C4(C)C ; Cc1cc2c(cc1N1c3cc4c(cc3B3c5cc6sc7ccc(C(C)(C)C)cc7c6cc5N(c5ccccc5-c5ccccc5)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(C(C)(C)C)cc1c53)C(C)(C)c1ccccc1C4(C)C)C(C)(C)CCC2(C)C]

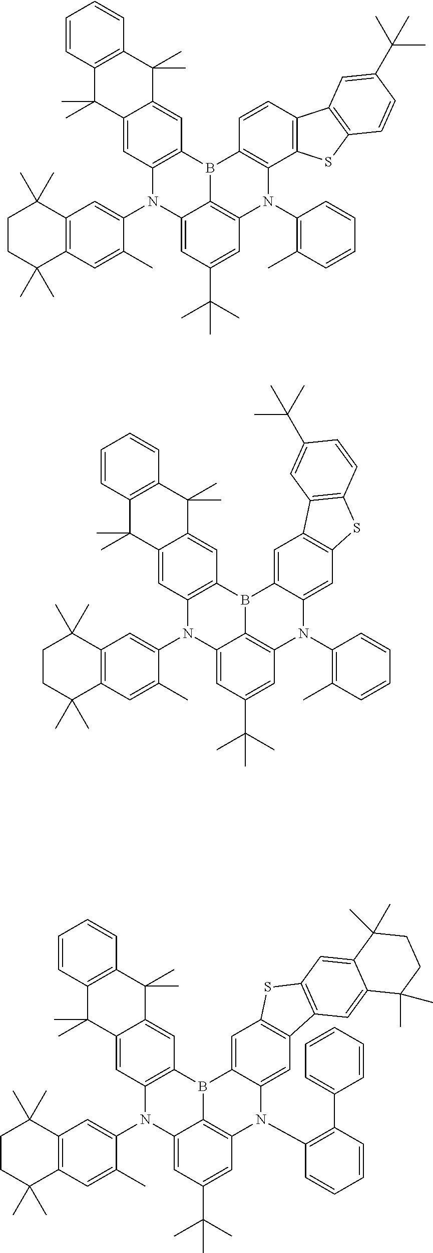 [SMILES: Cc1cc2c(cc1N1c3cc4c(cc3B3c5ccc6c(sc7ccc(C(C)(C)C)cc76)c5N(c5ccccc5C)c5cc(C(C)(C)C)cc1c53)C(C)(C)c1ccccc1C4(C)C)C(C)(C)CCC2(C)C ; Cc1ccccc1N1c2cc3sc4ccc(C(C)(C)C)cc4c3cc2B2c3cc4c(cc3N(c3cc5c(cc3C)C(C)(C)CCC5(C)C)c3cc(C(C)(C)C)cc1c32)C(C)(C)c1ccccc1C4(C)C ; Cc1cc2c(cc1N1c3cc4c(cc3B3c5cc6sc7cc8c(cc7c6cc5N(c5ccccc5-c5ccccc5)c5cc(C(C)(C)C)cc1c53)C(C)(C)CCC8(C)C)C(C)(C)c1ccccc1C4(C)C)C(C)(C)CCC2(C)C]

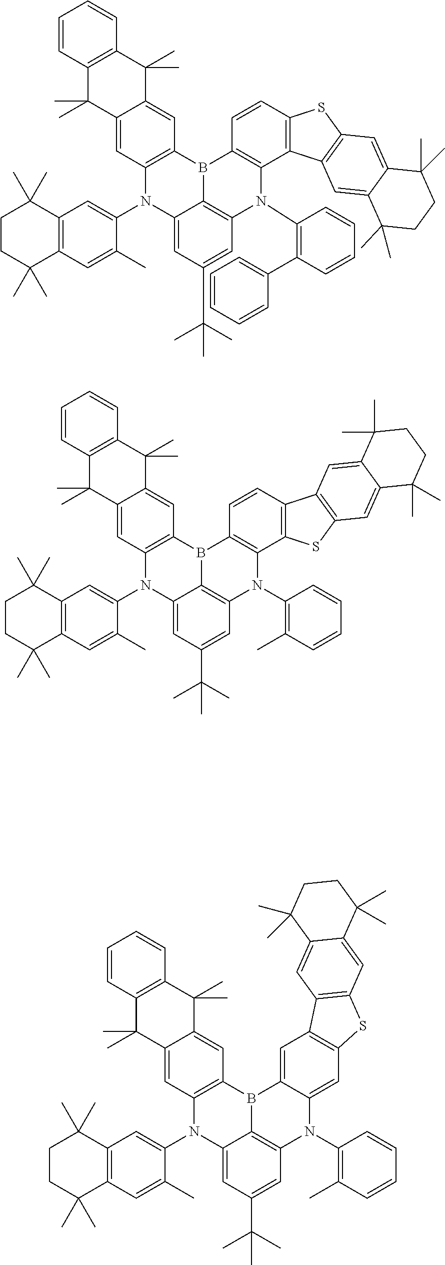 [SMILES: Cc1cc2c(cc1N1c3cc4c(cc3B3c5ccc6sc7cc8c(cc7c6c5N(c5ccccc5-c5ccccc5)c5cc(C(C)(C)C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(C(C)(C)C)cc1c53)C(C)(C)c1ccccc1C4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(C(C)(C)C)cc1c32)C(C)(C)c1ccccc1C4(C)C)C(C)(C)CCC5(C)C]

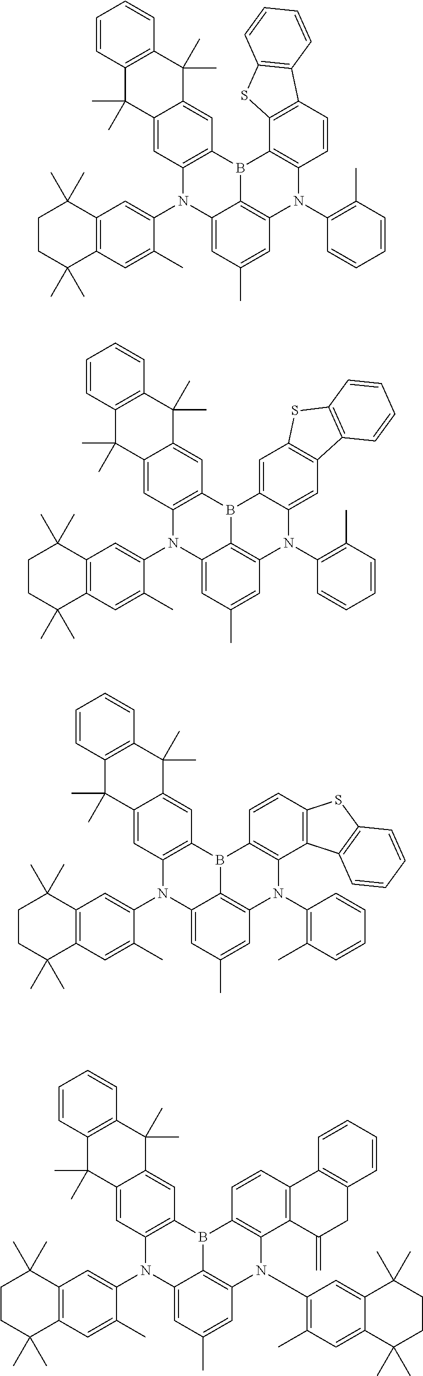 [SMILES: Cc1cc2c3c(c1)N(c1ccccc1C)c1ccc4c(sc5ccccc54)c1B3c1cc3c(cc1N2c1cc2c(cc1C)C(C)(C)CCC2(C)C)C(C)(C)c1ccccc1C3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)sc1ccccc14 ; Cc1cc2c3c(c1)N(c1ccccc1C)c1c(ccc4sc5ccccc5c14)B3c1cc3c(cc1N2c1cc2c(cc1C)C(C)(C)CCC2(C)C)C(C)(C)c1ccccc1C3(C)C ; C=C1Cc2ccccc2-c2ccc3c(c21)N(c1cc2c(cc1C)C(C)(C)CCC2(C)C)c1cc(C)cc2c1B3c1cc3c(cc1N2c1cc2c(cc1C)C(C)(C)CCC2(C)C)C(C)(C)c1ccccc1C3(C)C]

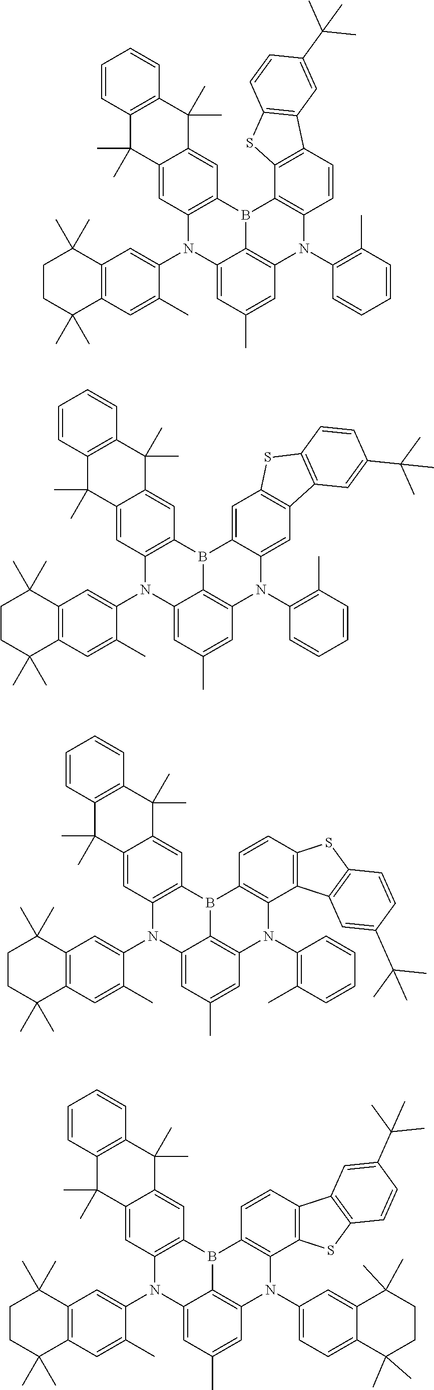

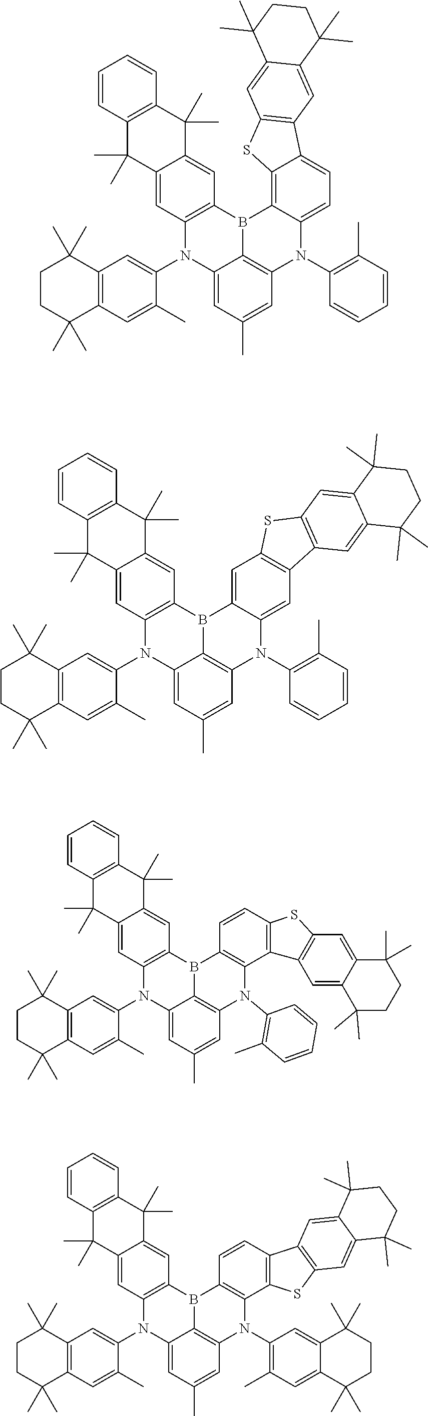

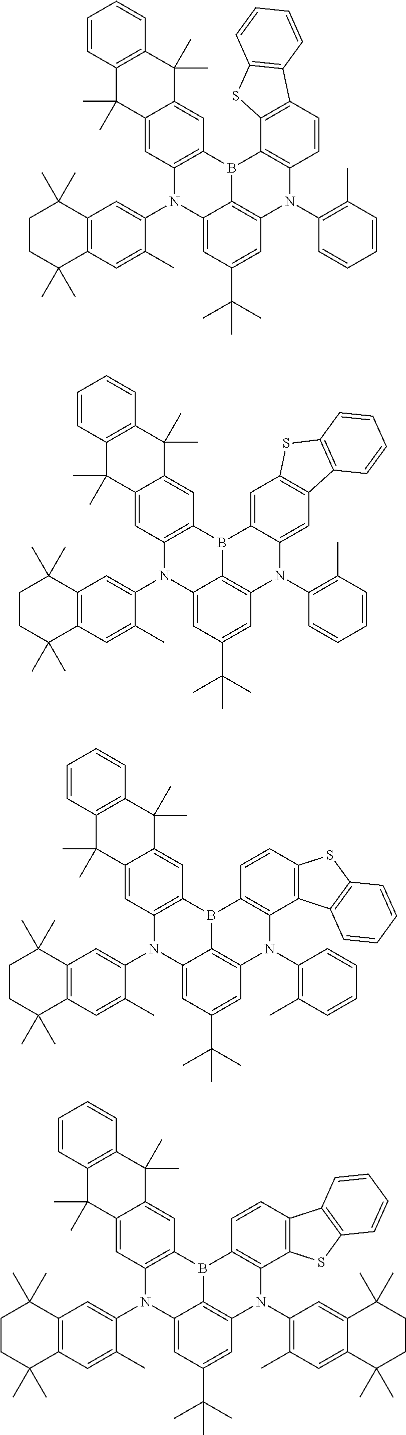 [SMILES: Cc1cc2c(cc1N1c3cc4c(cc3B3c5c1cc(C(C)(C)C)cc5N(c1ccccc1C)c1ccc5c(sc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)sc1ccccc13 ; Cc1cc2c(cc1N1c3cc4c(cc3B3c5ccc6sc7ccccc7c6c5N(c5ccccc5C)c5cc(C(C)(C)C)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(C(C)(C)C)cc1c53)C(C)(C)c1ccccc1C4(C)C)C(C)(C)CCC2(C)C]

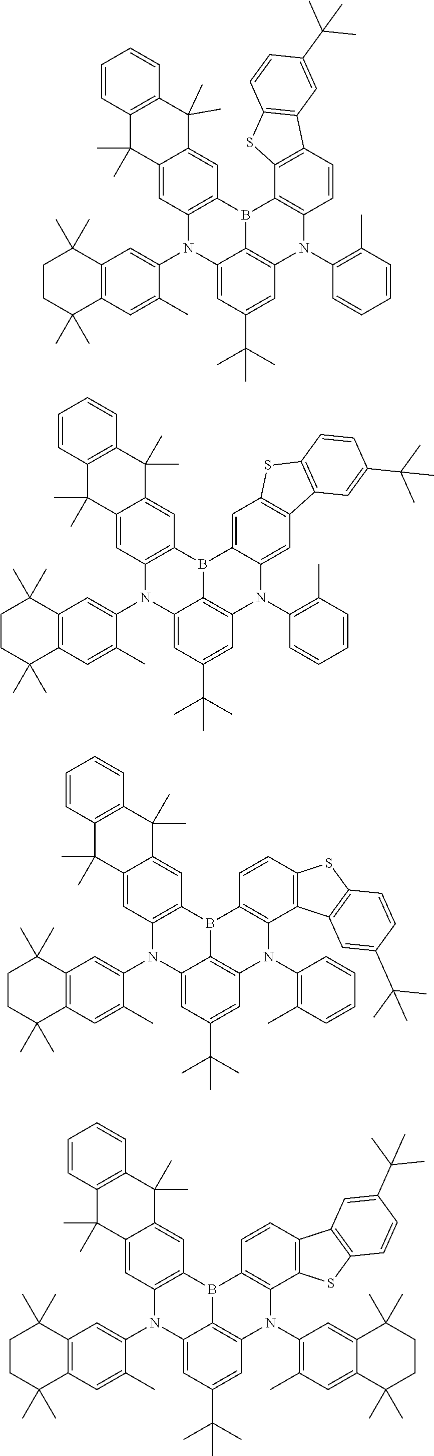

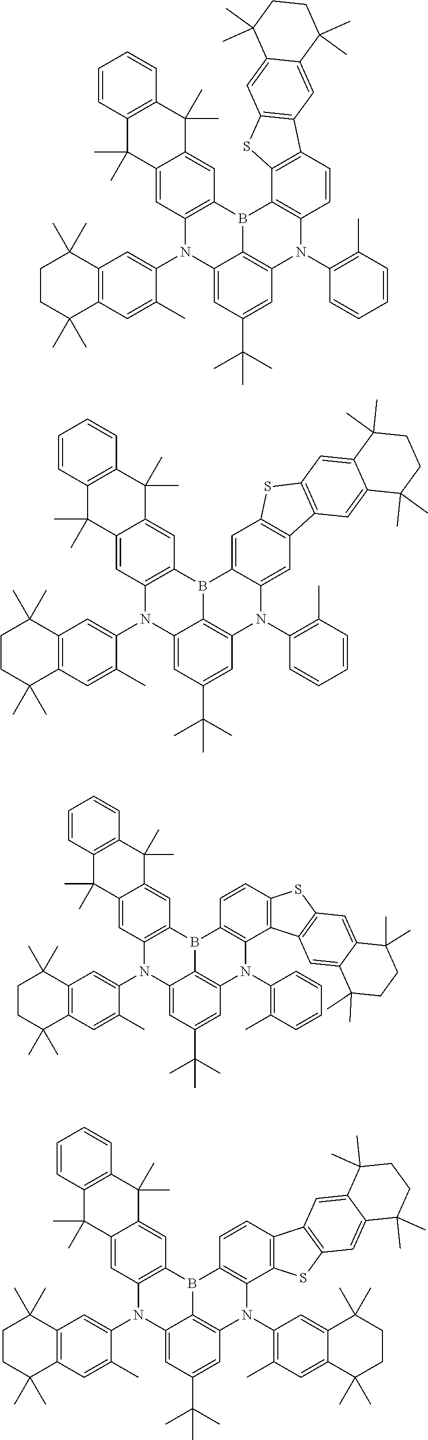

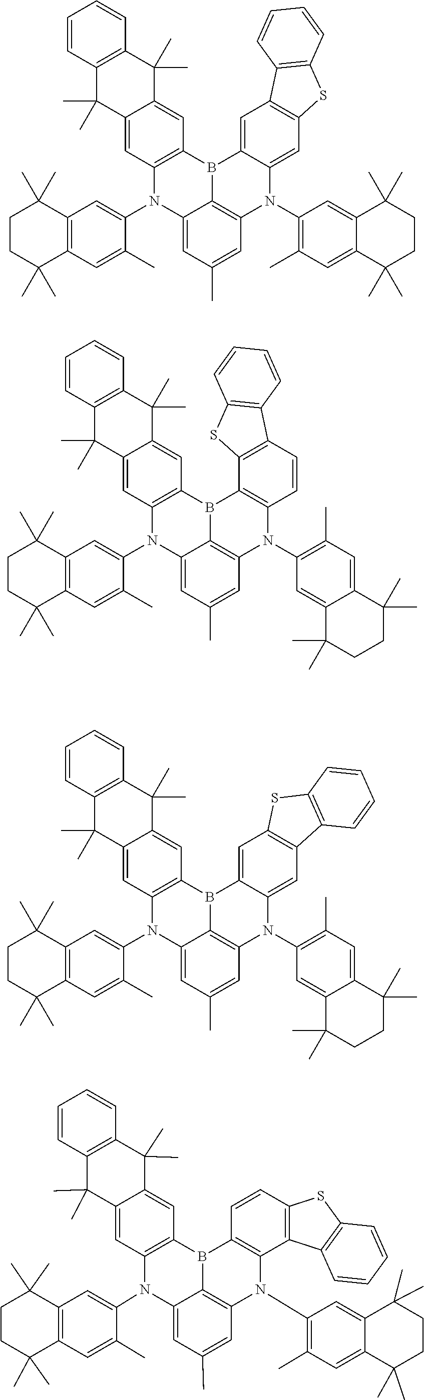

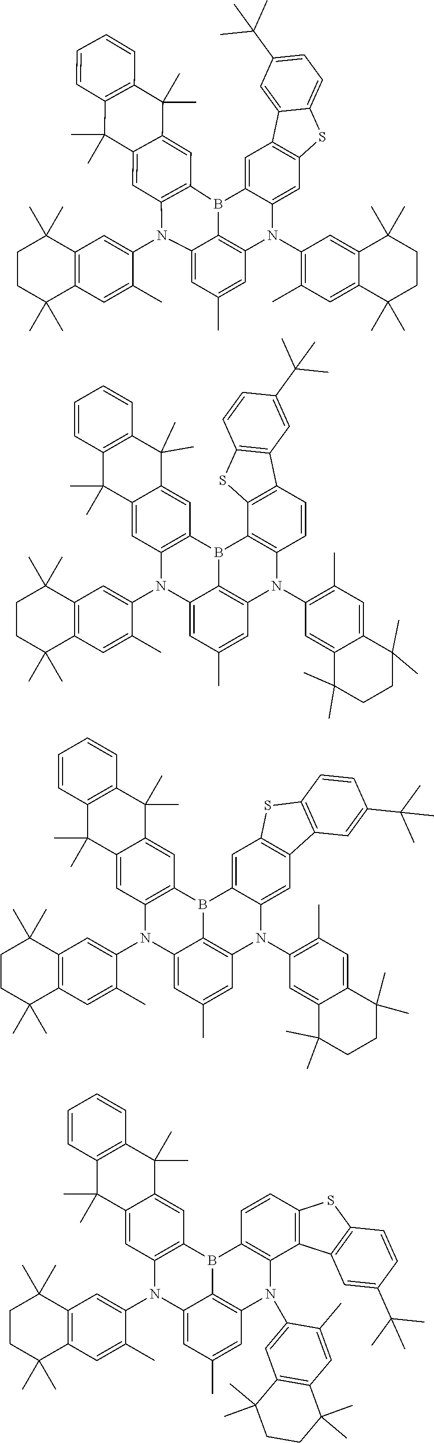

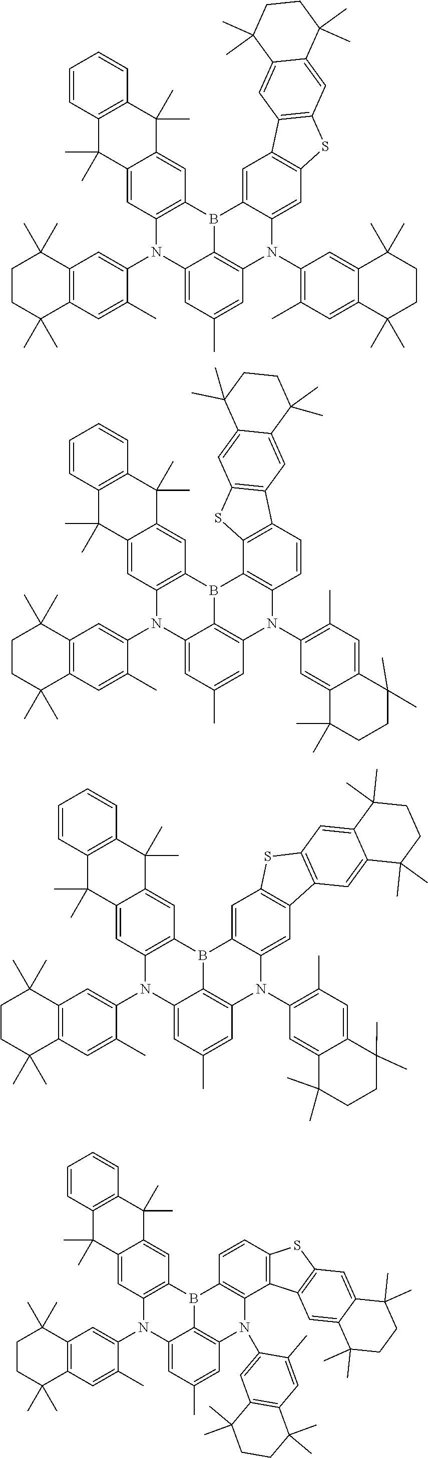

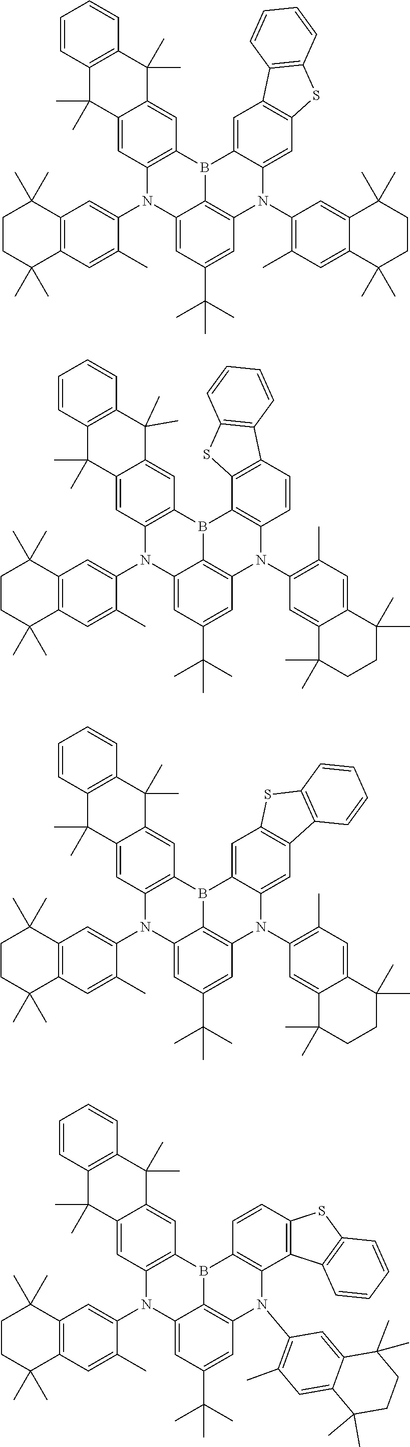

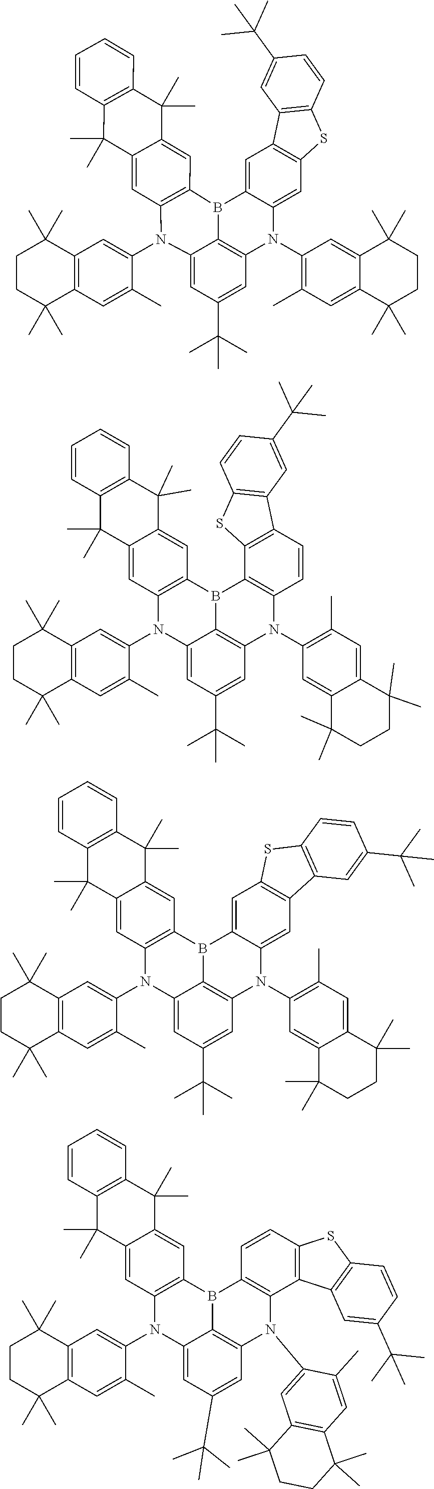

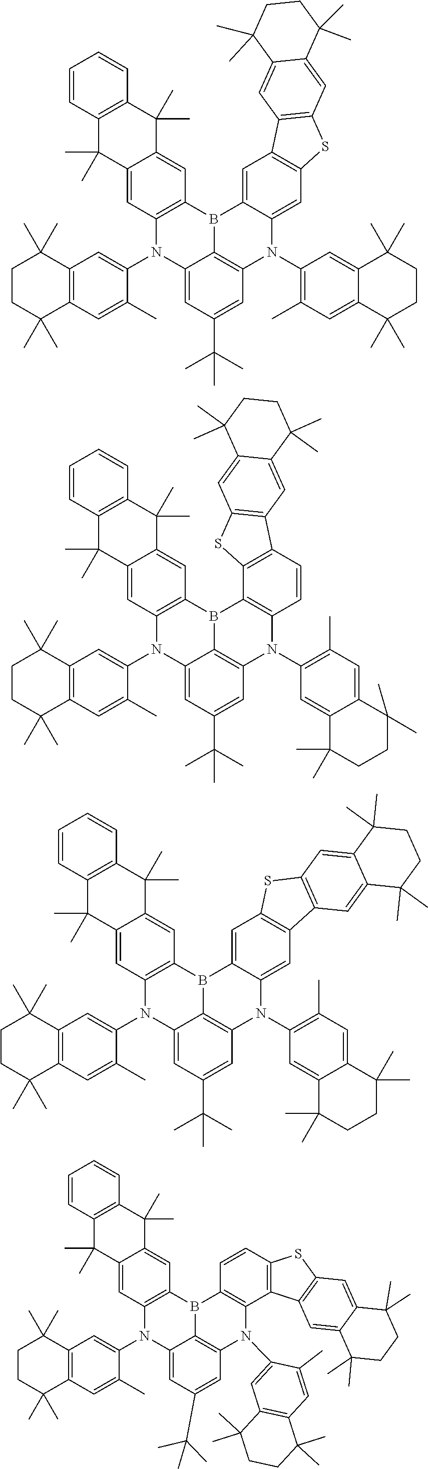

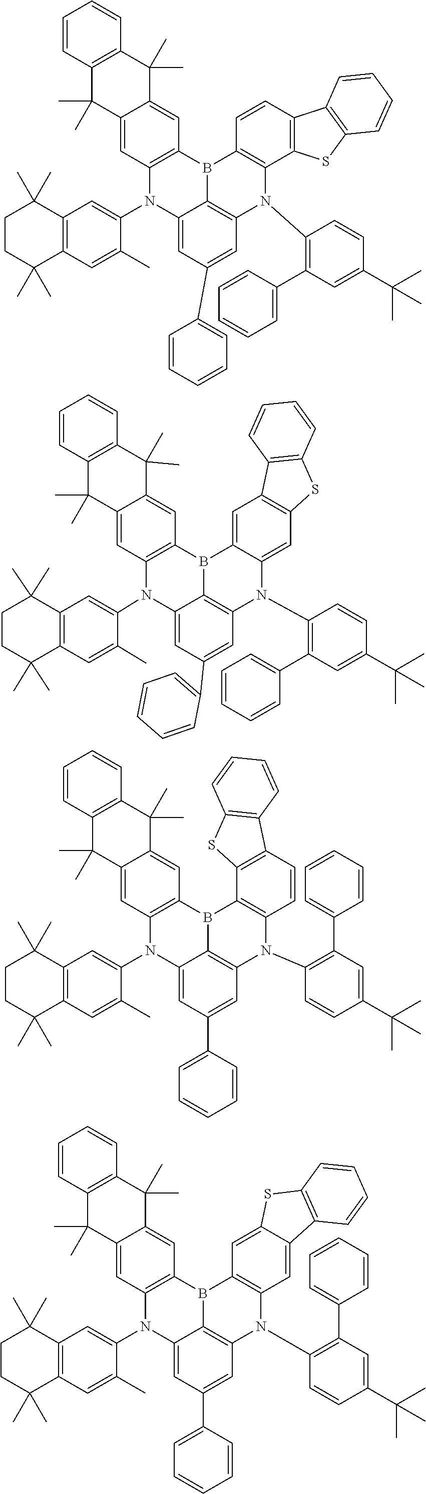

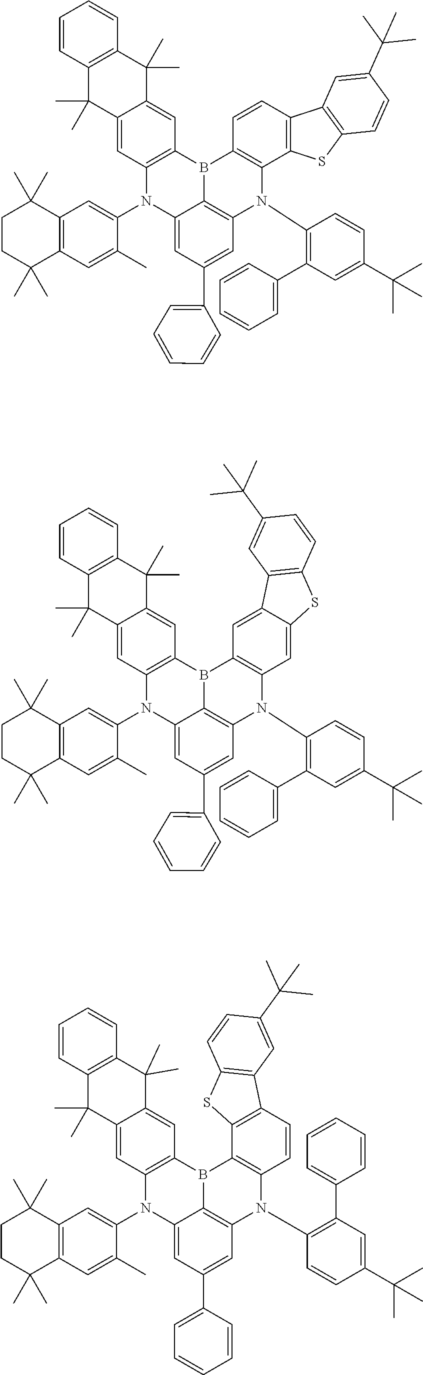 [SMILES: Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)sc1ccc(C(C)(C)C)cc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(sc6ccc(C(C)(C)C)cc65)c13)C(C)(C)c1ccccc1C4(C)C)C(C)(C)CCC2(C)C]

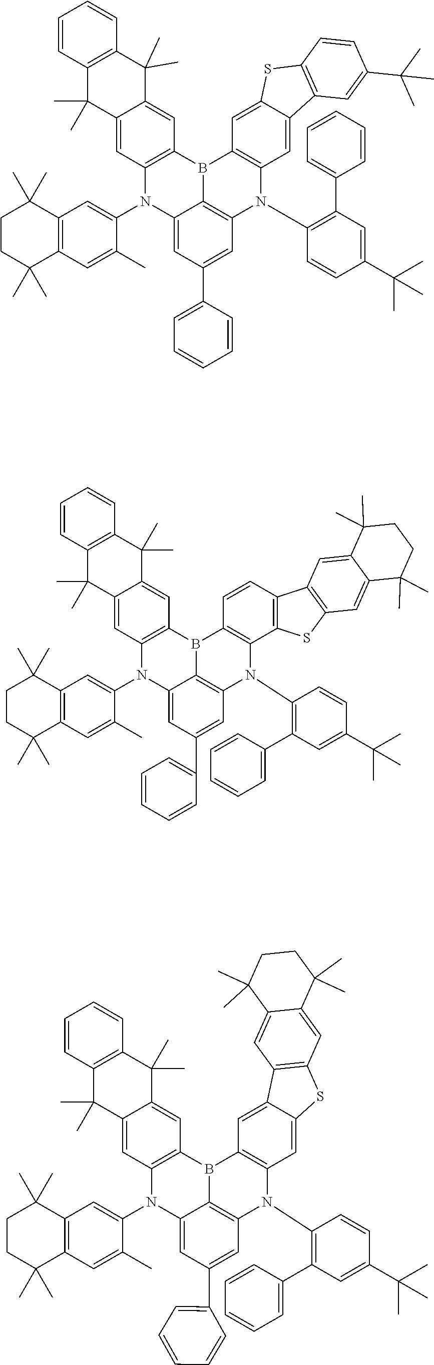 [SMILES: Cc1cc2c(cc1N1c3cc4c(cc3B3c5cc6sc7ccc(C(C)(C)C)cc7c6cc5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)sc1cc3c(cc16)C(C)(C)CCC3(C)C)C(C)(C)c1ccccc1C4(C)C)C(C)(C)CCC2(C)C]

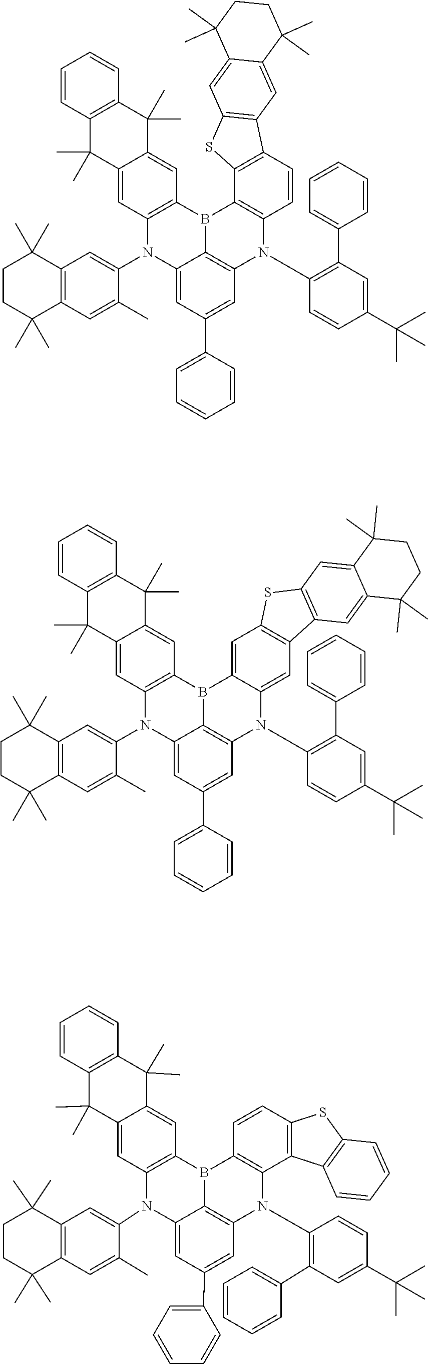 [SMILES: Cc1cc2c(cc1N1c3cc4c(cc3B3c5c1cc(-c1ccccc1)cc5N(c1ccc(C(C)(C)C)cc1-c1ccccc1)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7cc8c(cc7c6cc5N(c5ccc(C(C)(C)C)cc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7ccccc7c6c5N(c5ccc(C(C)(C)C)cc5-c5ccccc5)c5cc(-c6ccccc6)cc1c53)C(C)(C)c1ccccc1C4(C)C)C(C)(C)CCC2(C)C]

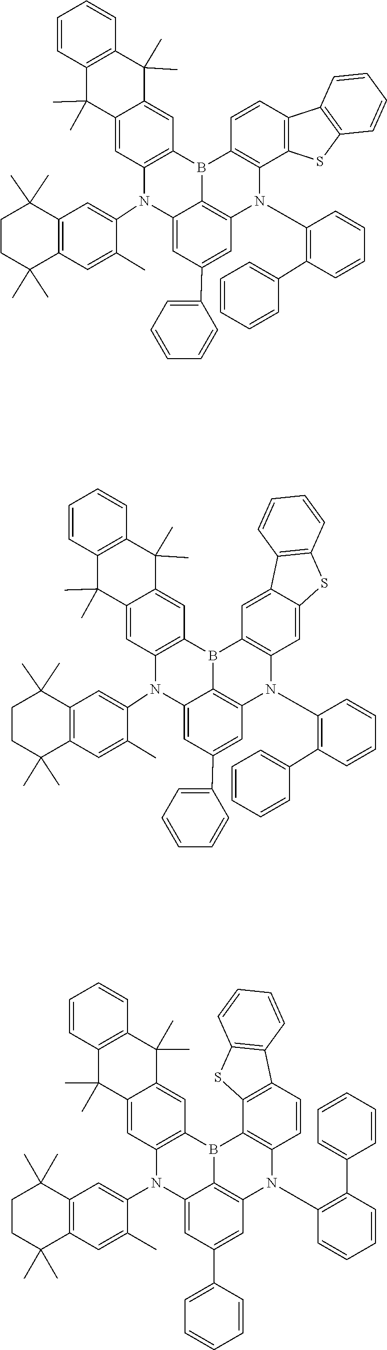 [SMILES: Cc1cc2c(cc1N1c3cc4c(cc3B3c5ccc6c(sc7ccccc76)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)sc1ccccc16)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(sc6ccccc65)c13)C(C)(C)c1ccccc1C4(C)C)C(C)(C)CCC2(C)C]

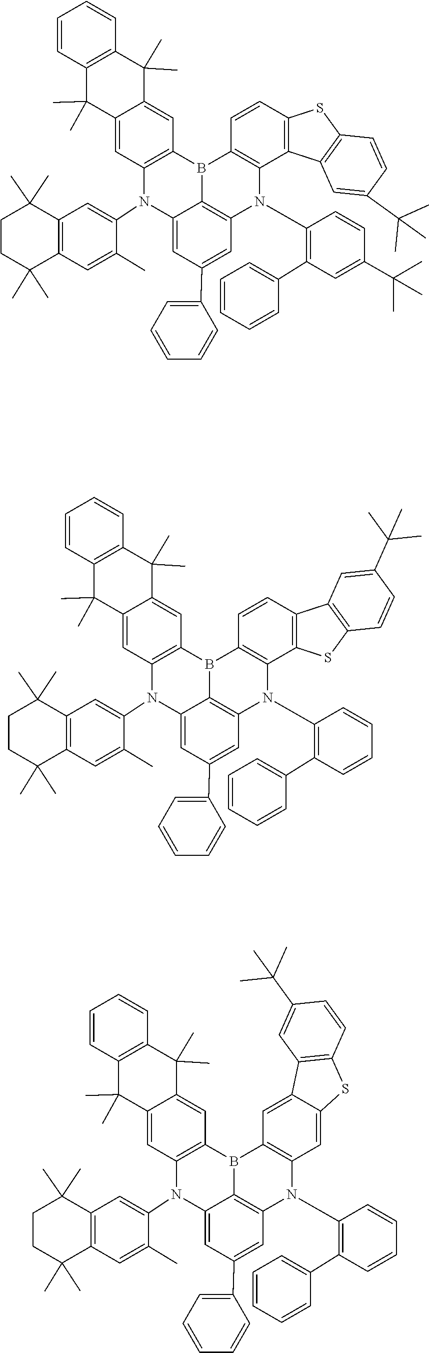 [SMILES: Cc1cc2c(cc1N1c3cc4c(cc3B3c5ccc6sc7ccc(C(C)(C)C)cc7c6c5N(c5ccc(C(C)(C)C)cc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)sc1ccc(C(C)(C)C)cc16)C(C)(C)c1ccccc1C4(C)C)C(C)(C)CCC2(C)C]

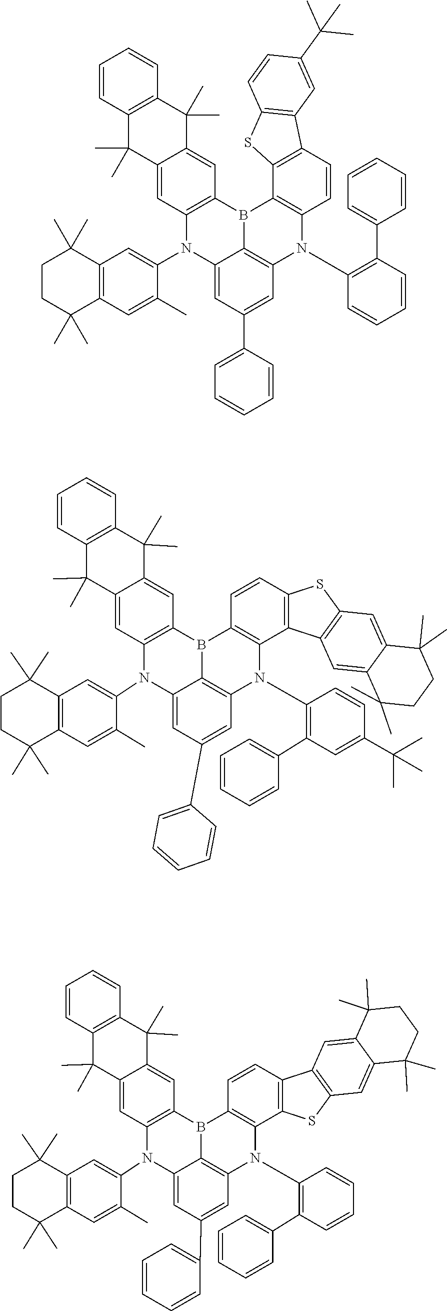 [SMILES: Cc1cc2c(cc1N1c3cc4c(cc3B3c5c1cc(-c1ccccc1)cc5N(c1ccccc1-c1ccccc1)c1ccc5c(sc6ccc(C(C)(C)C)cc65)c13)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5-c5ccccc5)c5cc(-c6ccccc6)cc1c53)C(C)(C)c1ccccc1C4(C)C)C(C)(C)CCC2(C)C]

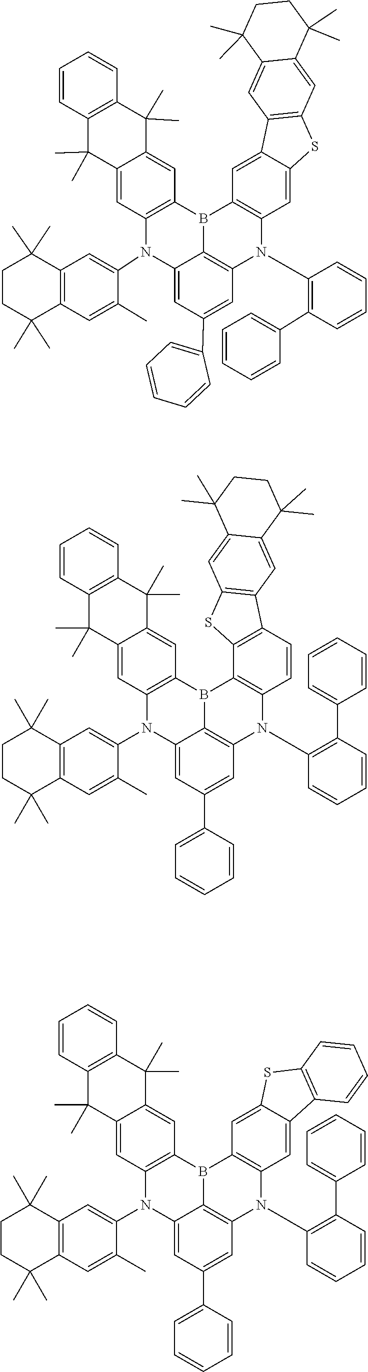 [SMILES: Cc1cc2c(cc1N1c3cc4c(cc3B3c5cc6c(cc5N(c5ccccc5-c5ccccc5)c5cc(-c7ccccc7)cc1c53)sc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1-c1ccccc1)c1ccc5c(sc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6sc7ccccc7c6cc5N(c5ccccc5-c5ccccc5)c5cc(-c6ccccc6)cc1c53)C(C)(C)c1ccccc1C4(C)C)C(C)(C)CCC2(C)C]

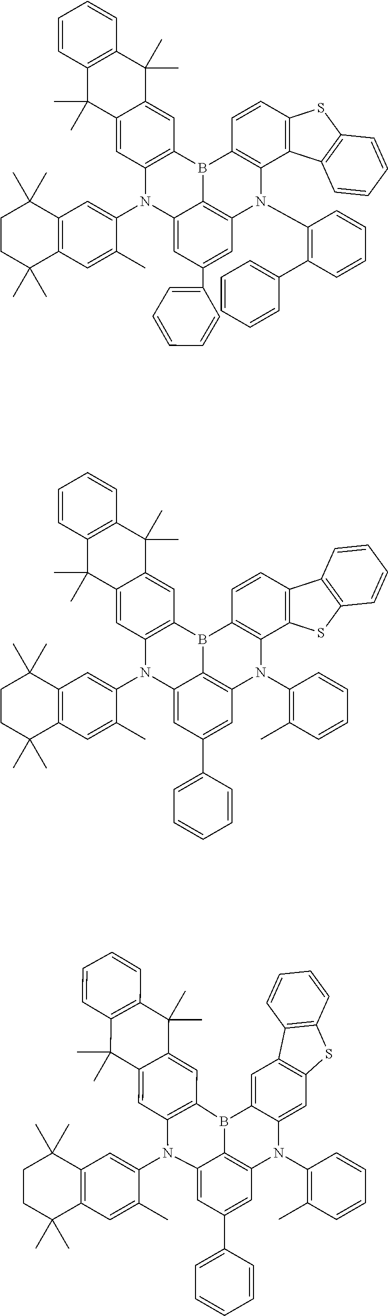 [SMILES: Cc1cc2c(cc1N1c3cc4c(cc3B3c5ccc6sc7ccccc7c6c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5C)c5cc(-c6ccccc6)cc1c53)C(C)(C)c1ccccc1C4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(-c5ccccc5)cc1c32)C(C)(C)c1ccccc1C4(C)C]

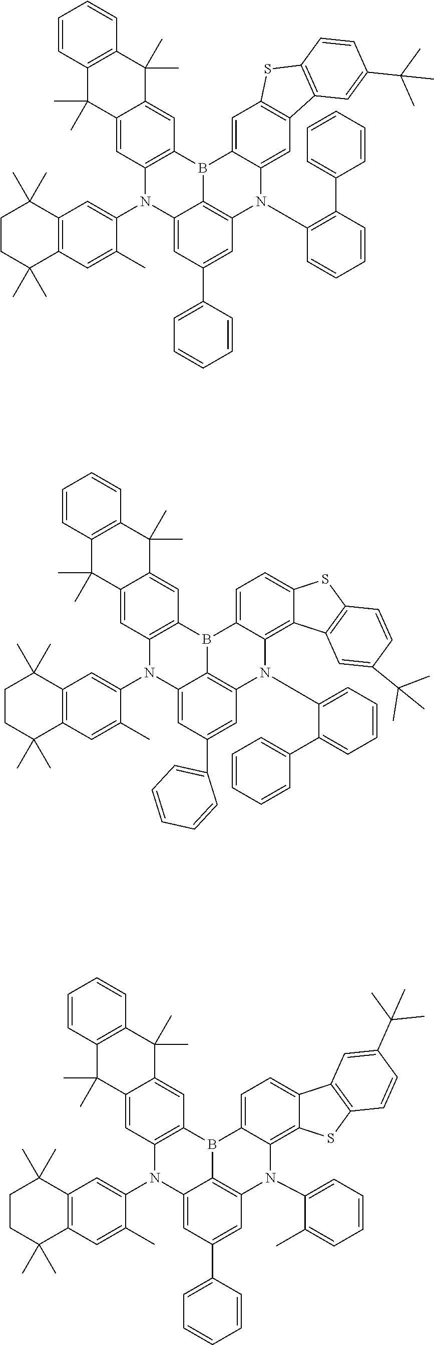 [SMILES: Cc1cc2c(cc1N1c3cc4c(cc3B3c5cc6sc7ccc(C(C)(C)C)cc7c6cc5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(-c6ccccc6)cc1c53)C(C)(C)c1ccccc1C4(C)C)C(C)(C)CCC2(C)C]

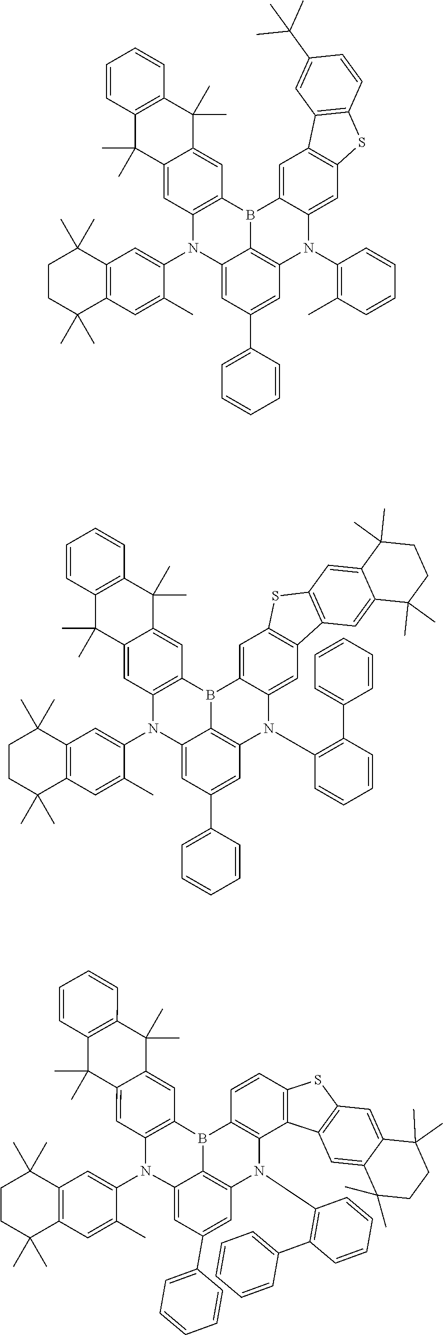 [SMILES: Cc1ccccc1N1c2cc3sc4ccc(C(C)(C)C)cc4c3cc2B2c3cc4c(cc3N(c3cc5c(cc3C)C(C)(C)CCC5(C)C)c3cc(-c5ccccc5)cc1c32)C(C)(C)c1ccccc1C4(C)C ; Cc1cc2c(cc1N1c3cc4c(cc3B3c5cc6sc7cc8c(cc7c6cc5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(-c6ccccc6)cc1c53)C(C)(C)CCC8(C)C)C(C)(C)c1ccccc1C4(C)C)C(C)(C)CCC2(C)C]

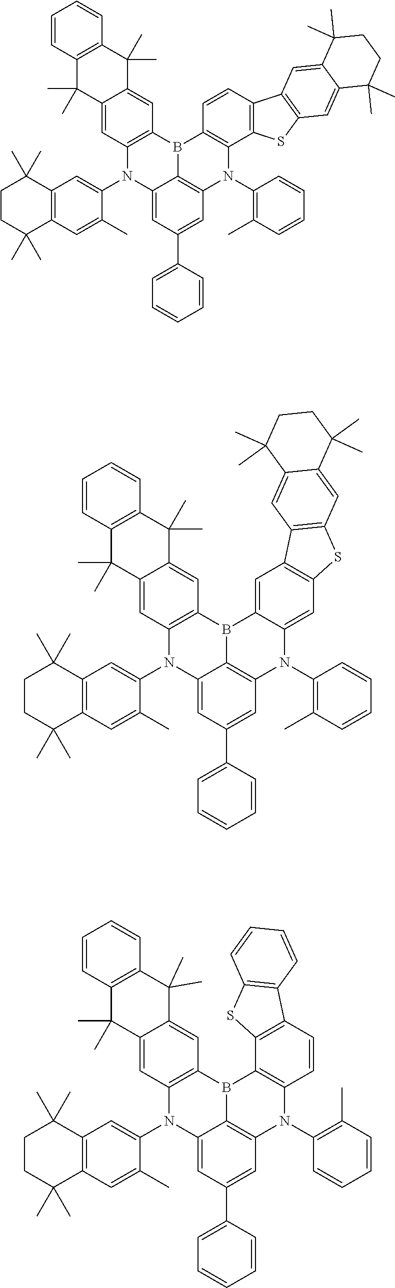 [SMILES: Cc1cc2c(cc1N1c3cc4c(cc3B3c5ccc6c(sc7cc8c(cc76)C(C)(C)CCC8(C)C)c5N(c5ccccc5C)c5cc(-c6ccccc6)cc1c53)C(C)(C)c1ccccc1C4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(-c6ccccc6)cc1c32)C(C)(C)c1ccccc1C4(C)C)C(C)(C)CCC5(C)C ; Cc1cc2c(cc1N1c3cc4c(cc3B3c5c1cc(-c1ccccc1)cc5N(c1ccccc1C)c1ccc5c(sc6ccccc65)c13)C(C)(C)c1ccccc1C4(C)C)C(C)(C)CCC2(C)C]

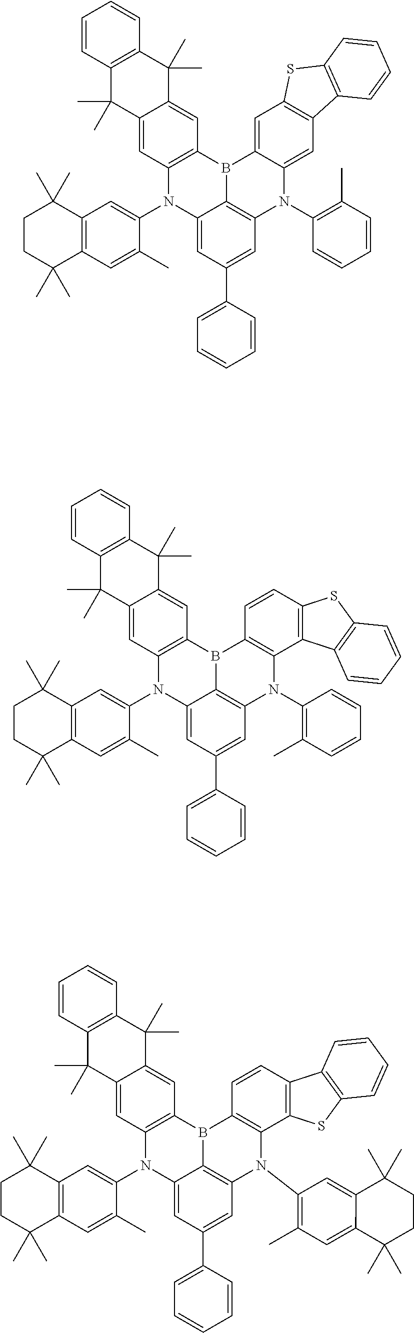 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)sc1ccccc13 ; Cc1cc2c(cc1N1c3cc4c(cc3B3c5ccc6sc7ccccc7c6c5N(c5ccccc5C)c5cc(-c6ccccc6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C]

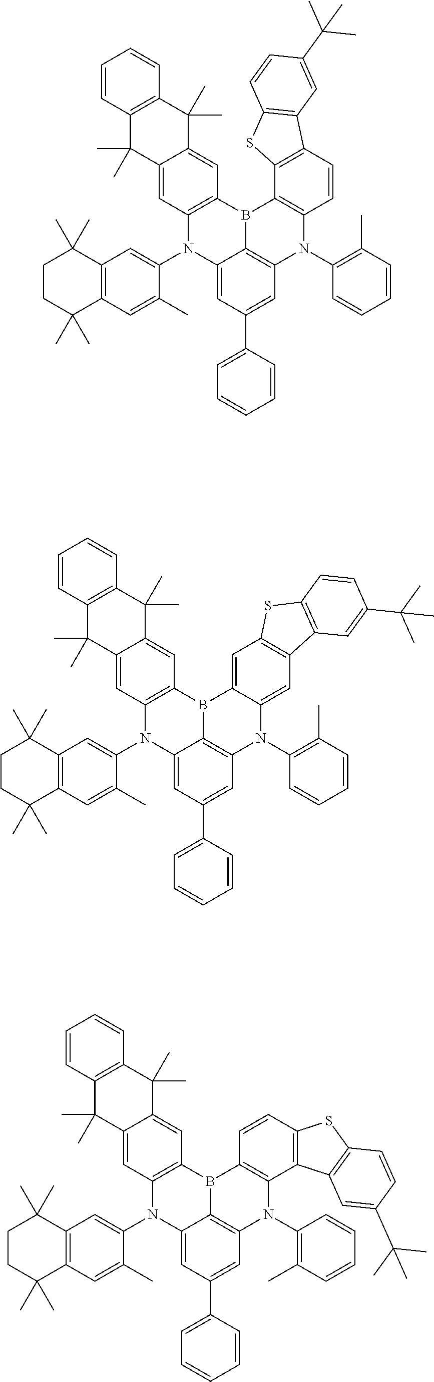 [SMILES: Cc1cc2c(cc1N1c3cc4c(cc3B3c5c1cc(-c1ccccc1)cc5N(c1ccccc1C)c1ccc5c(sc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)sc1ccc(C(C)(C)C)cc13 ; Cc1cc2c(cc1N1c3cc4c(cc3B3c5ccc6sc7ccc(C(C)(C)C)cc7c6c5N(c5ccccc5C)c5cc(-c6ccccc6)cc1c53)C(C)(C)c1ccccc1C4(C)C)C(C)(C)CCC2(C)C]

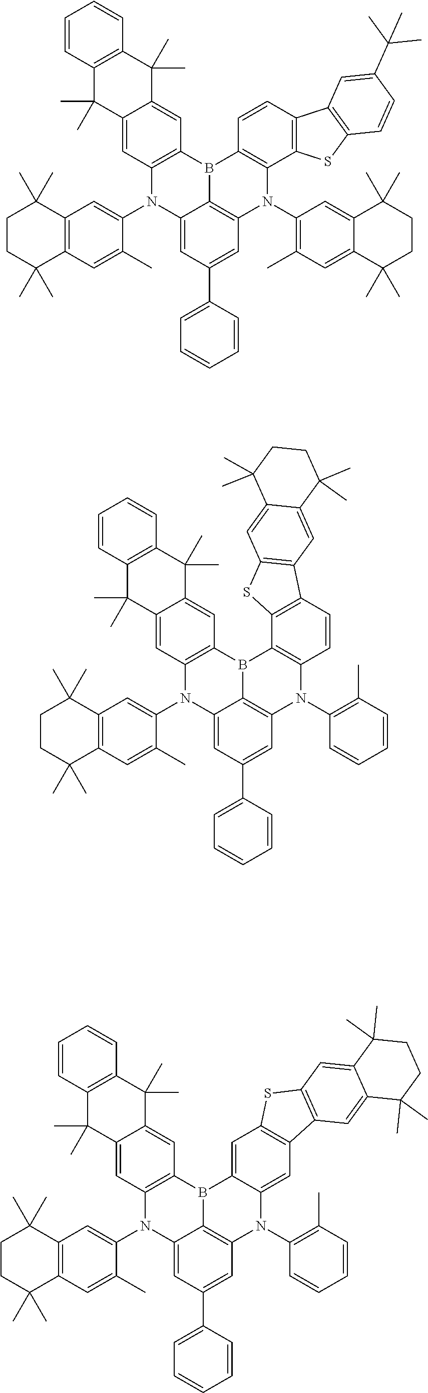 [SMILES: Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6ccccc6)cc1c53)C(C)(C)c1ccccc1C4(C)C)C(C)(C)CCC2(C)C ; Cc1cc2c(cc1N1c3cc4c(cc3B3c5c1cc(-c1ccccc1)cc5N(c1ccccc1C)c1ccc5c(sc6cc7c(cc65)C(C)(C)CCC7(C)C)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1C5(C)C)sc1cc2c(cc13)C(C)(C)CCC2(C)C]

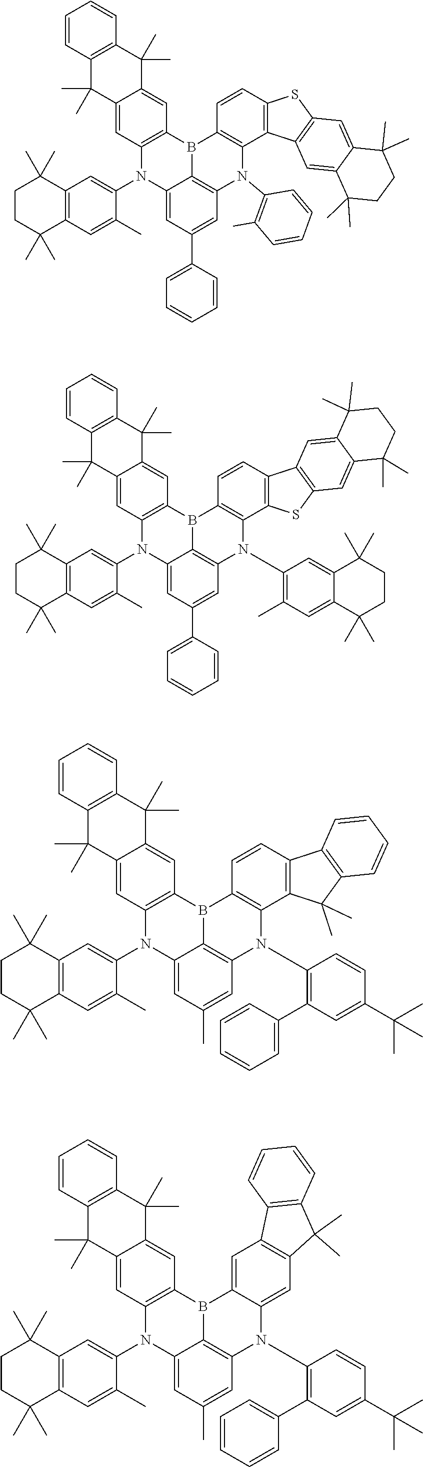

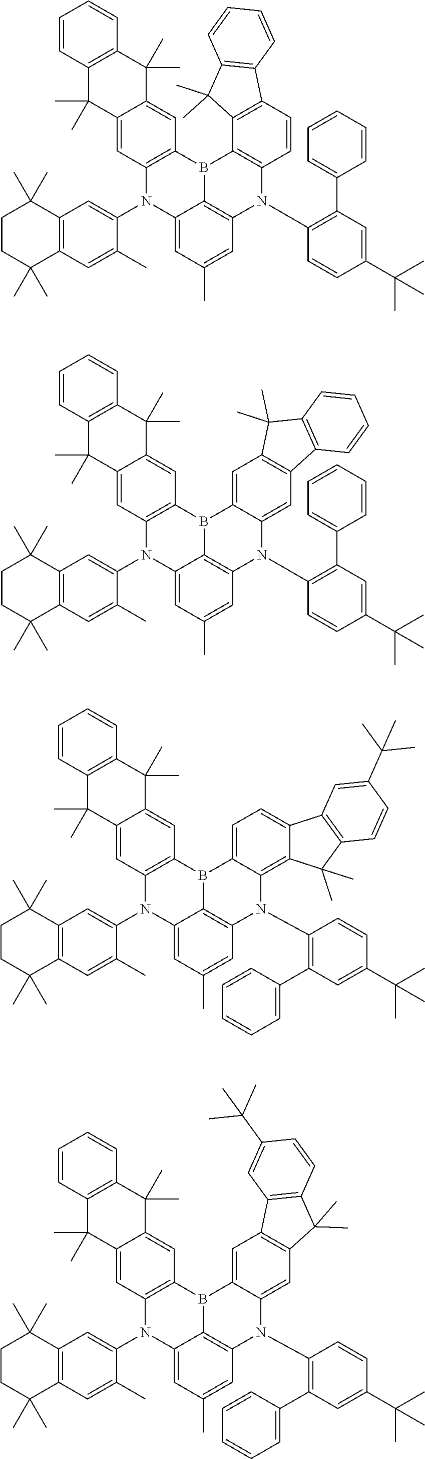

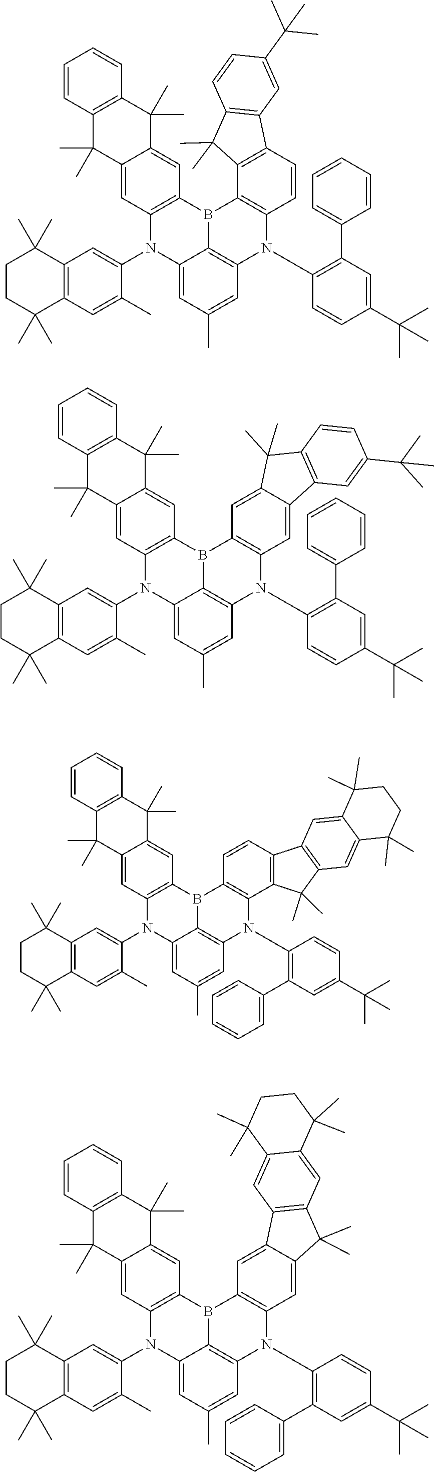

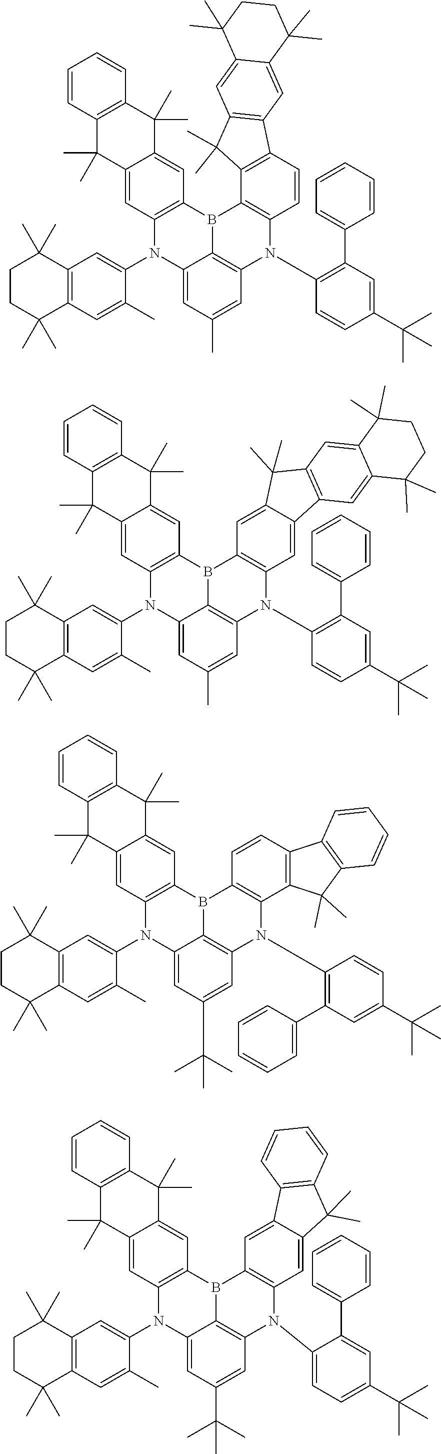

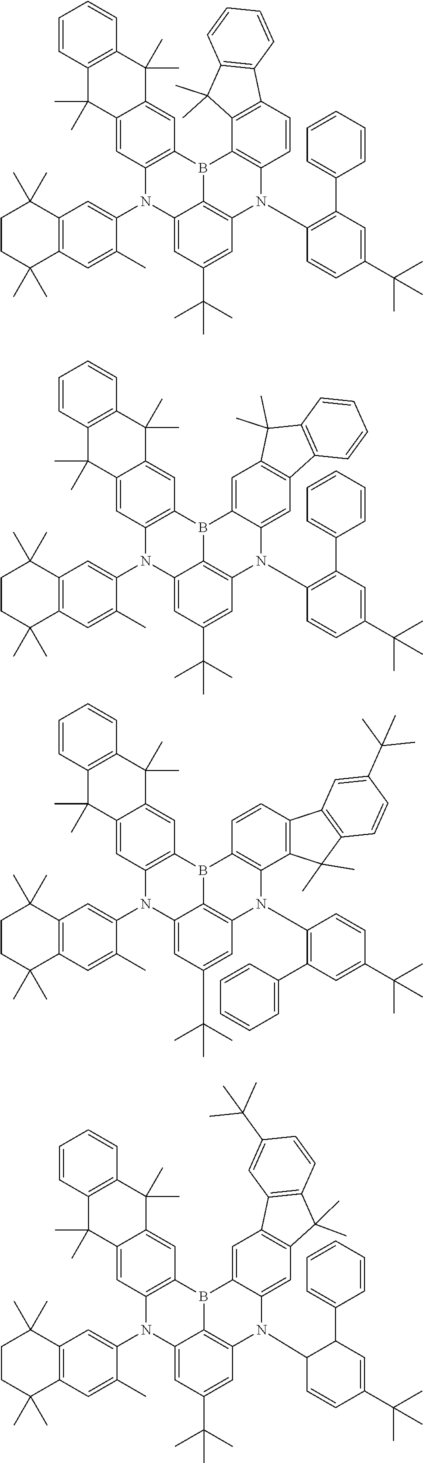

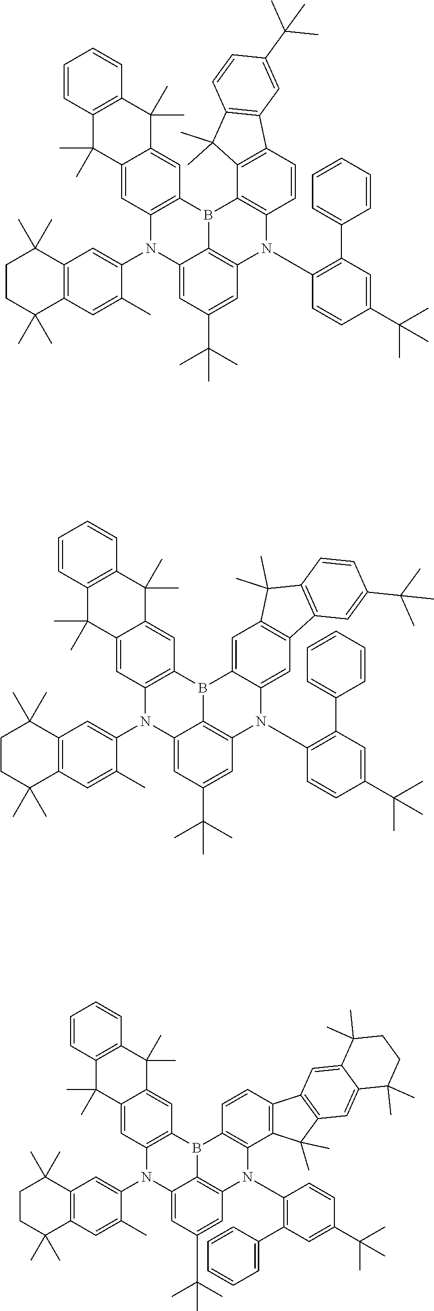 [SMILES: Cc1cc2c(cc1N1c3cc4c(cc3B3c5c1cc(C(C)(C)C)cc5N(c1ccc(C(C)(C)C)cc1-c1ccccc1)c1ccc5c(c13)C(C)(C)c1ccc(C(C)(C)C)cc1-5)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C]

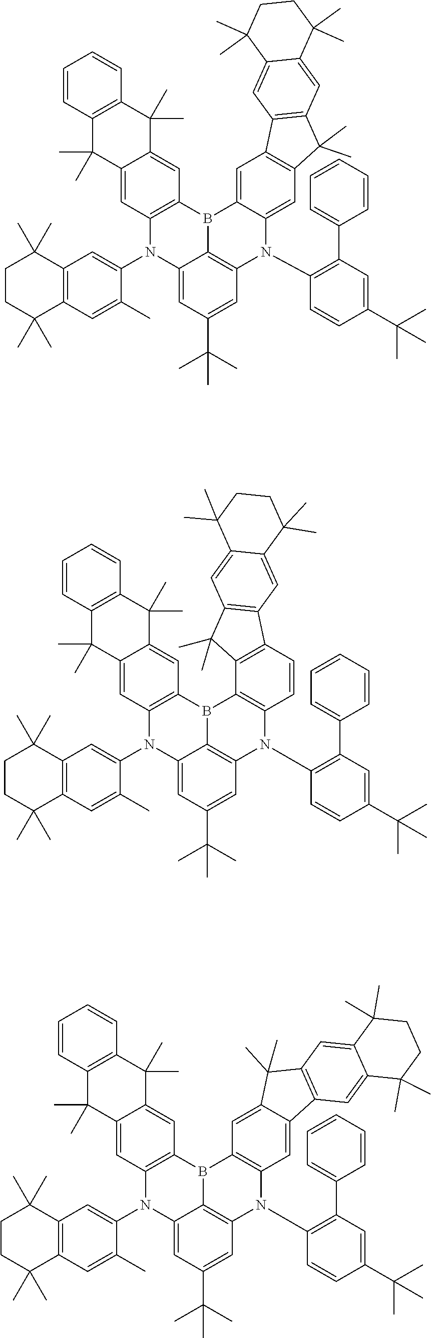 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(c13)C(C)(C)c1cc3c(cc1-5)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)-c1cc3c(cc1C6(C)C)C(C)(C)CCC3(C)C)C(C)(C)c1ccccc1C4(C)C)C(C)(C)CCC2(C)C]

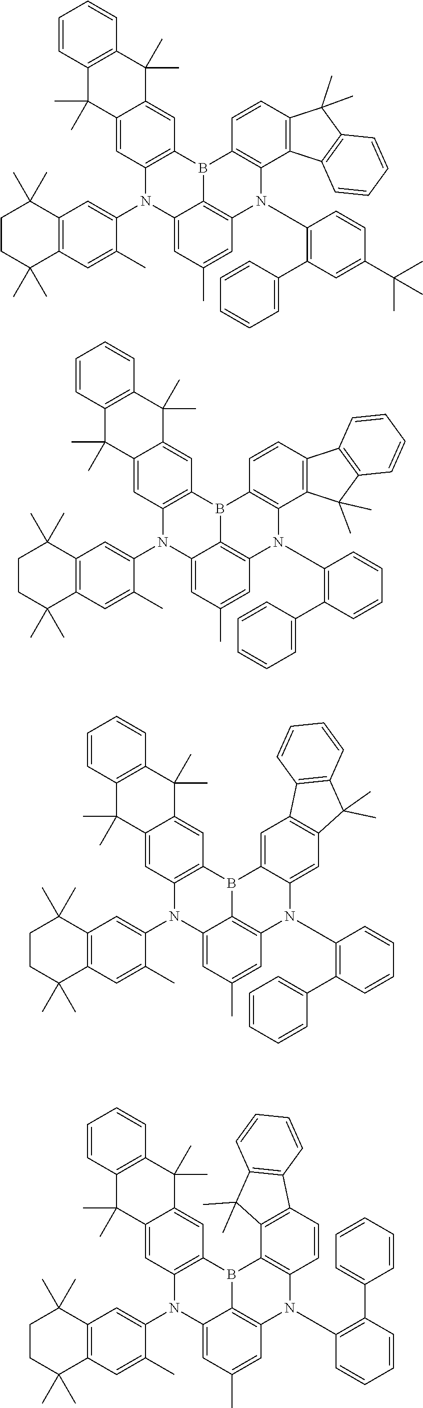

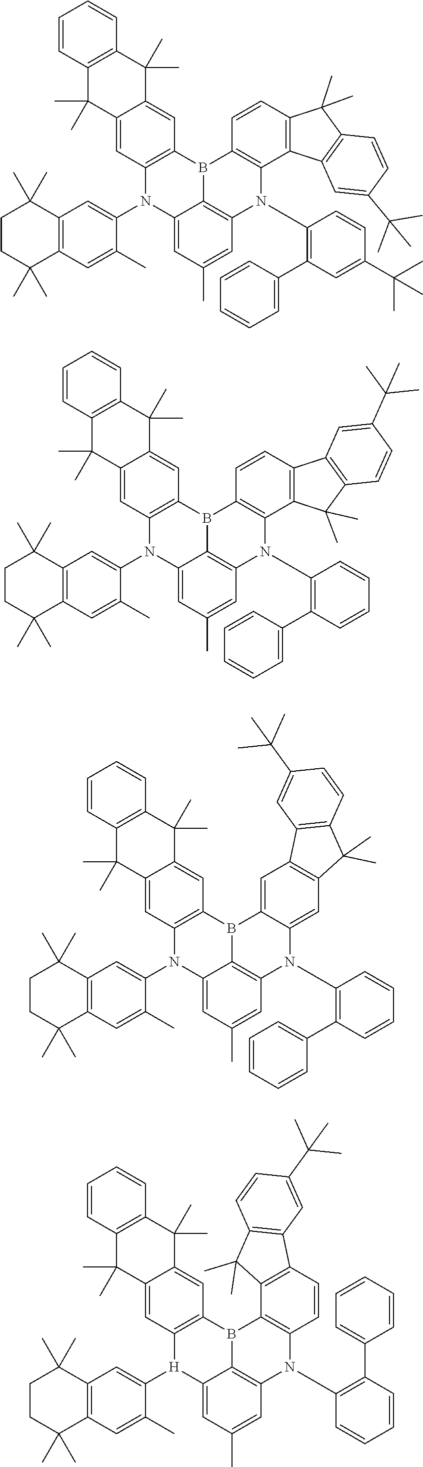

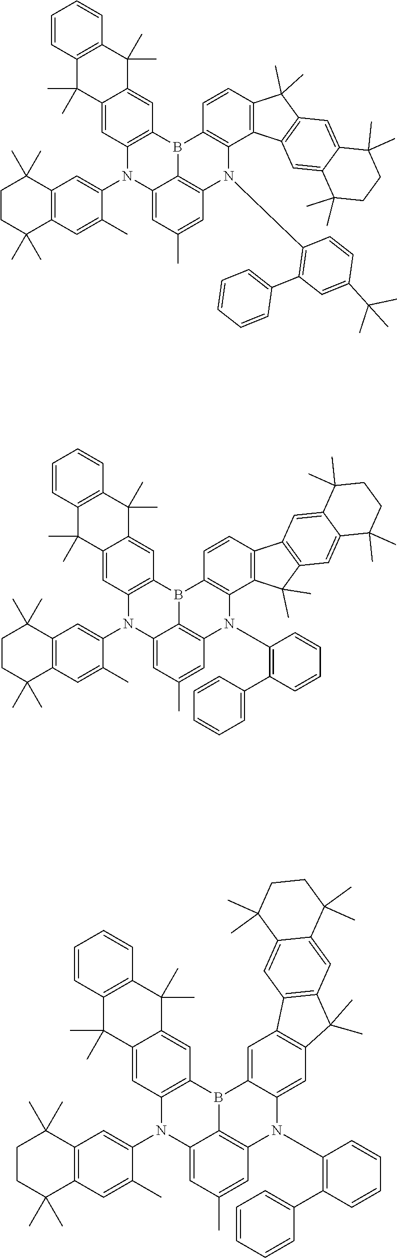 [SMILES: Cc1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)c1ccccc1C3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)-c1cc2c(cc1C4(C)C)C(C)(C)CCC2(C)C]

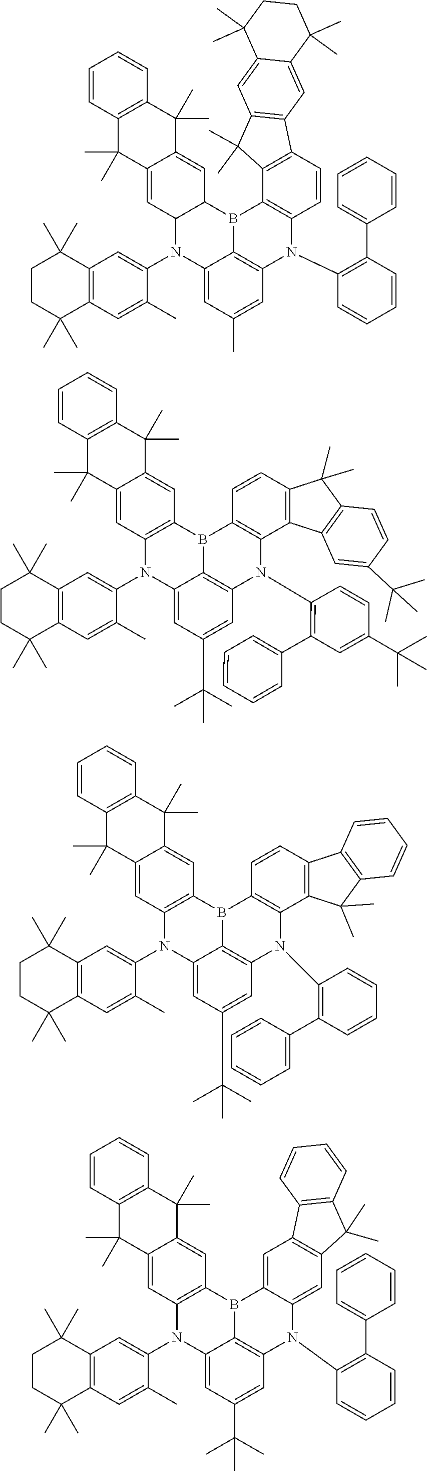

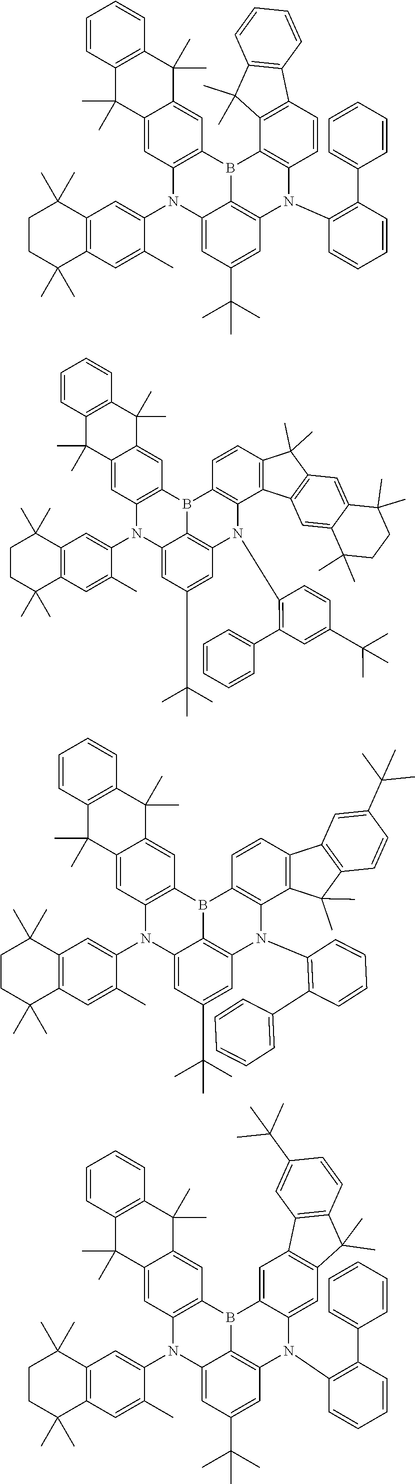

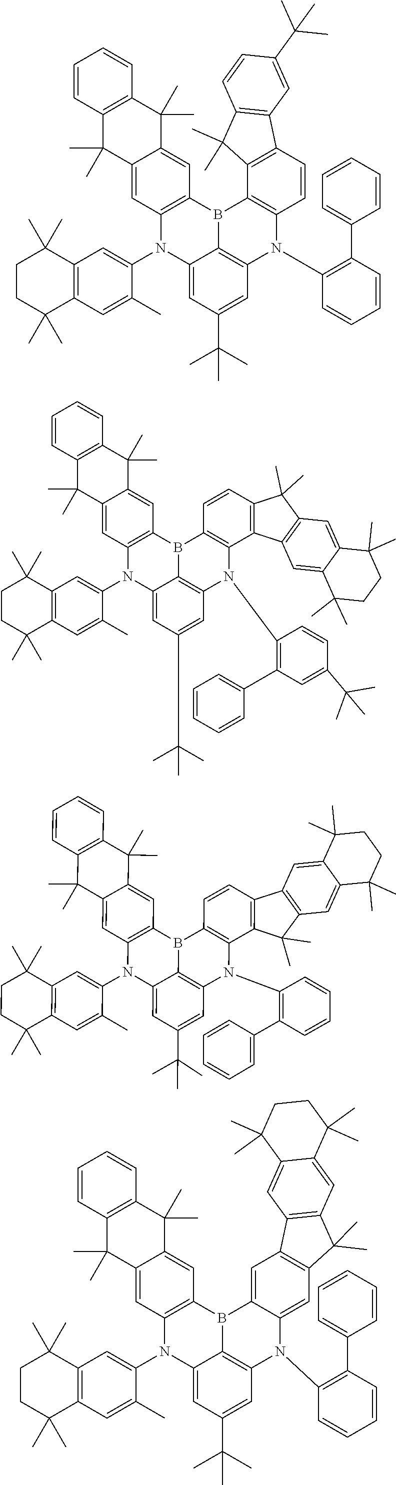

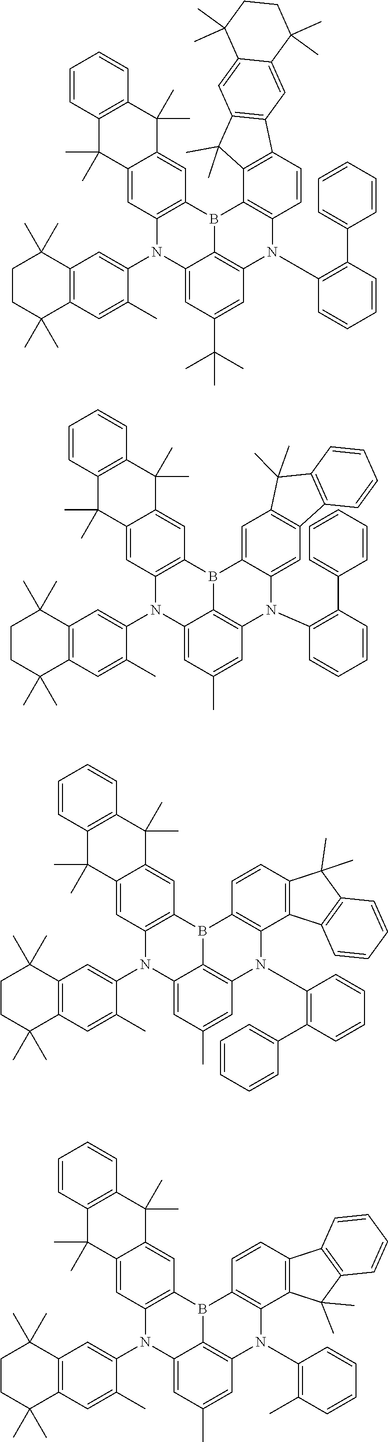

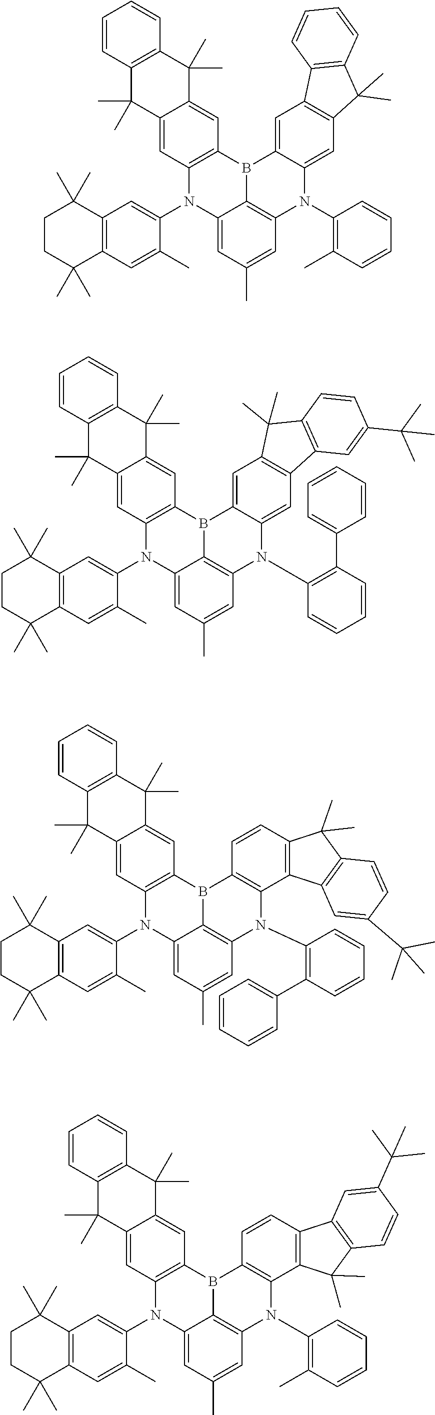

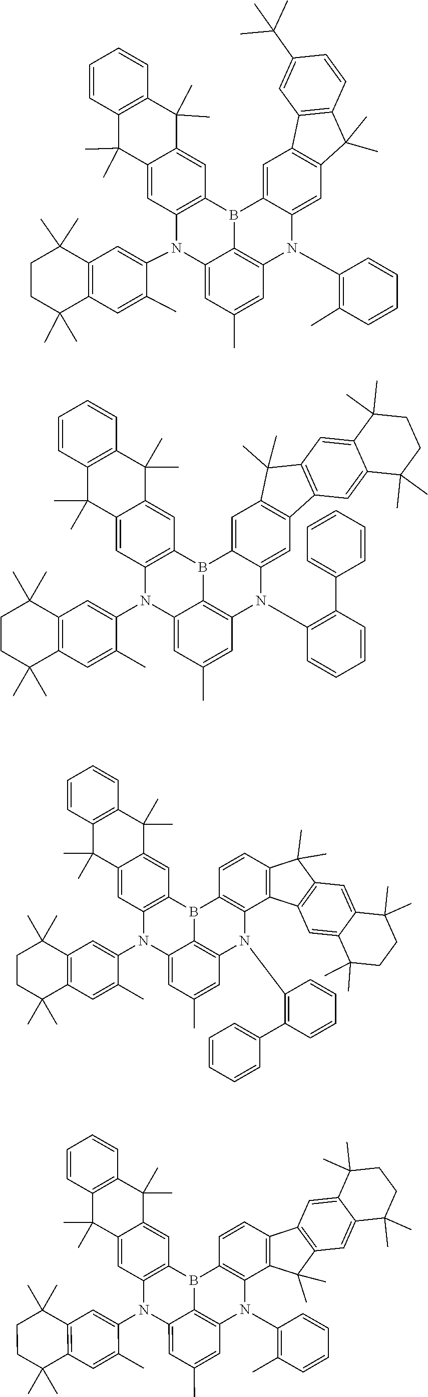

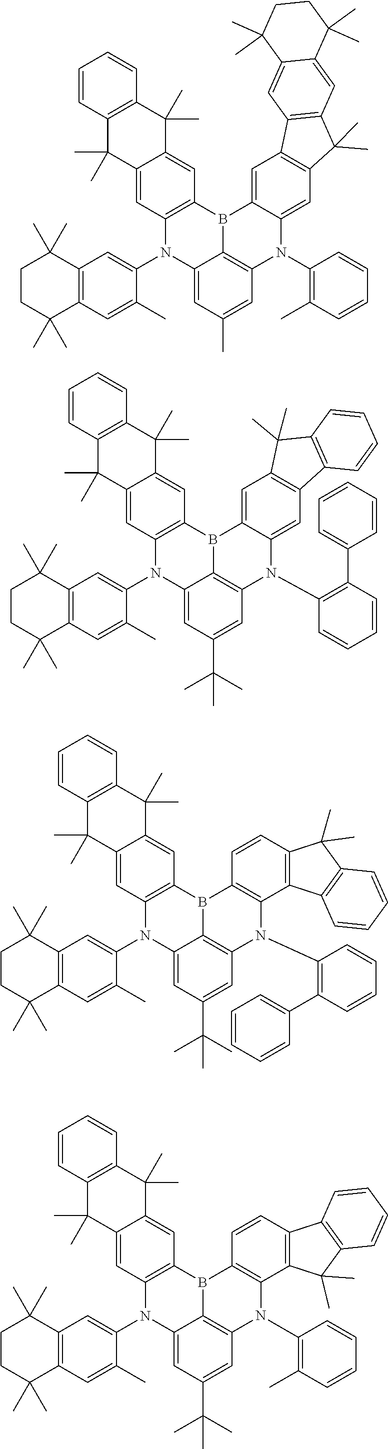

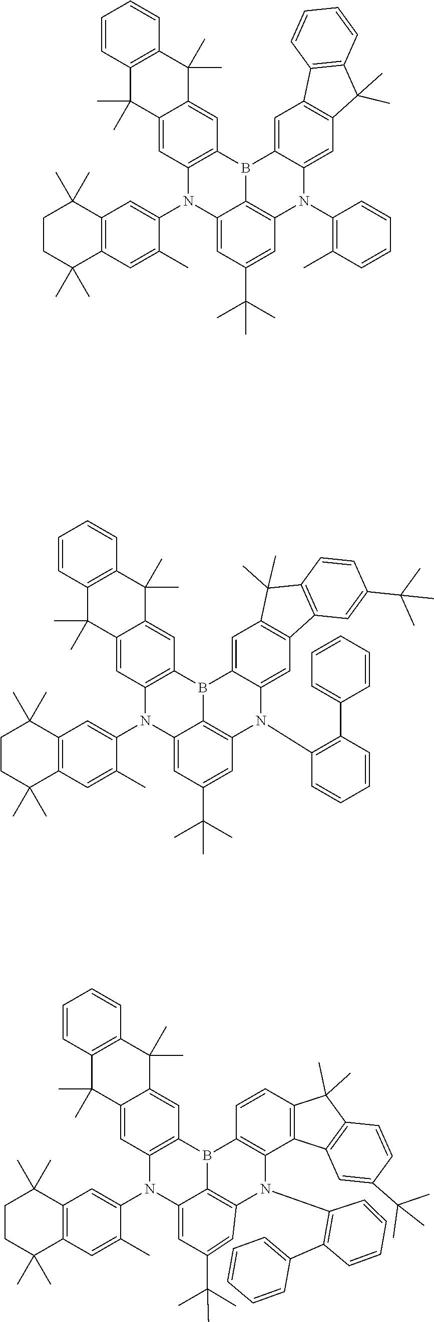 [SMILES: Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)-c1ccccc1C3(C)C ; Cc1cc2c(cc1N1c3cc4c(cc3B3c5cc6c(cc5N(c5ccccc5-c5ccccc5)c5cc(C(C)(C)C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)-c1cc(C(C)(C)C)ccc1C6(C)C)C(C)(C)c1ccccc1C4(C)C)C(C)(C)CCC2(C)C]

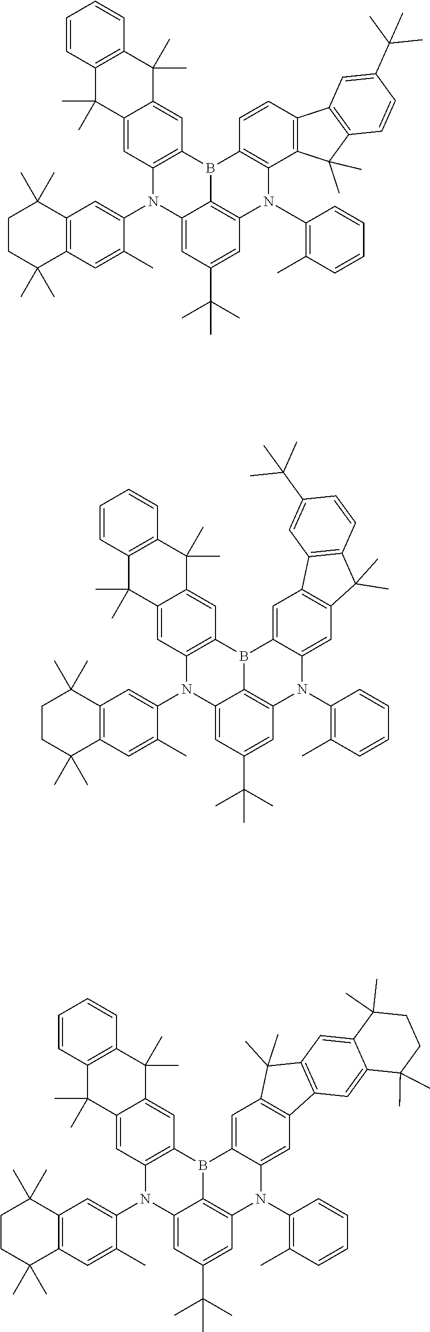 [SMILES: Cc1cc2c(cc1N1c3cc4c(cc3B3c5ccc6c(c5N(c5ccccc5C)c5cc(C(C)(C)C)cc1c53)C(C)(C)c1ccc(C(C)(C)C)cc1-6)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)-c1cc(C(C)(C)C)ccc1C3(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)C(C)(C)c1cc2c(cc1-3)C(C)(C)CCC2(C)C]

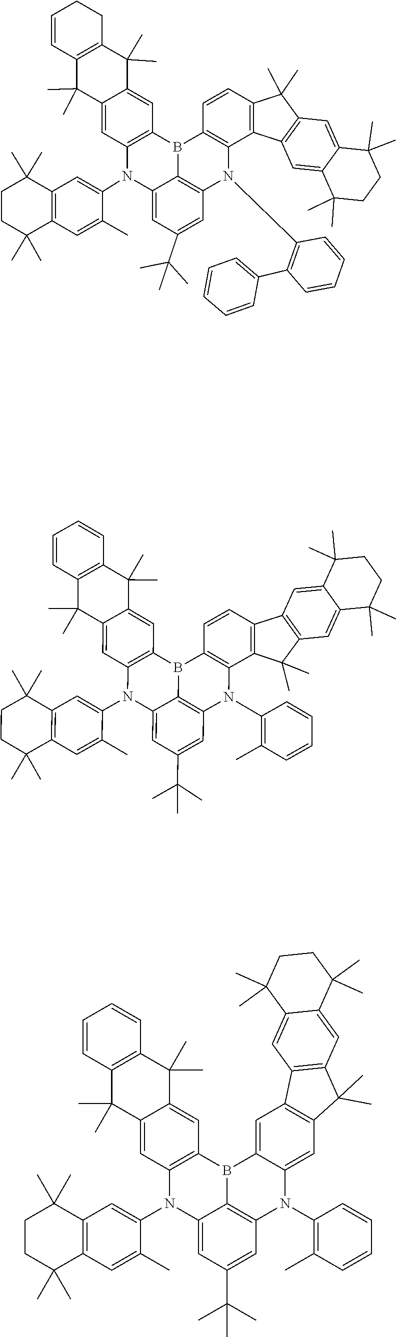 [SMILES: Cc1cc2c(cc1N1c3cc4c(cc3B3c5ccc6c(c5N(c5ccccc5-c5ccccc5)c5cc(C(C)(C)C)cc1c53)-c1cc3c(cc1C6(C)C)C(C)(C)CCC3(C)C)C(C)(C)C1=C(C=CCC1)C4(C)C)C(C)(C)CCC2(C)C ; Cc1cc2c(cc1N1c3cc4c(cc3B3c5ccc6c(c5N(c5ccccc5C)c5cc(C(C)(C)C)cc1c53)C(C)(C)c1cc3c(cc1-6)C(C)(C)CCC3(C)C)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)c1ccccc1C5(C)C)-c1cc2c(cc1C3(C)C)C(C)(C)CCC2(C)C]

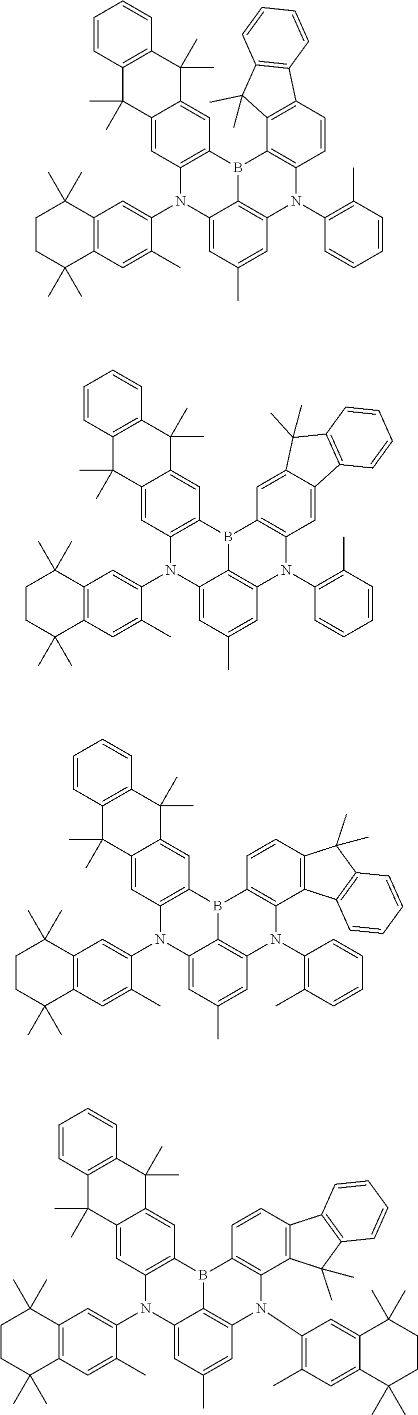 [SMILES: Cc1cc2c3c(c1)N(c1ccccc1C)c1ccc4c(c1B3c1cc3c(cc1N2c1cc2c(cc1C)C(C)(C)CCC2(C)C)C(C)(C)c1ccccc1C3(C)C)C(C)(C)c1ccccc1-4 ; Cc1cc2c3c(c1)N(c1cc4c(cc1C)C(C)(C)CCC4(C)C)c1cc4c(cc1B3c1cc3c(cc1N2c1ccccc1C)-c1ccccc1C3(C)C)C(C)(C)c1ccccc1C4(C)C ; Cc1cc2c3c(c1)N(c1ccccc1C)c1c(ccc4c1-c1ccccc1C4(C)C)B3c1cc3c(cc1N2c1cc2c(cc1C)C(C)(C)CCC2(C)C)C(C)(C)c1ccccc1C3(C)C ; Cc1cc2c3c(c1)N(c1cc4c(cc1C)C(C)(C)CCC4(C)C)c1c(ccc4c1C(C)(C)c1ccccc1-4)B3c1cc3c(cc1N2c1cc2c(cc1C)C(C)(C)CCC2(C)C)C(C)(C)c1ccccc1C3(C)C]

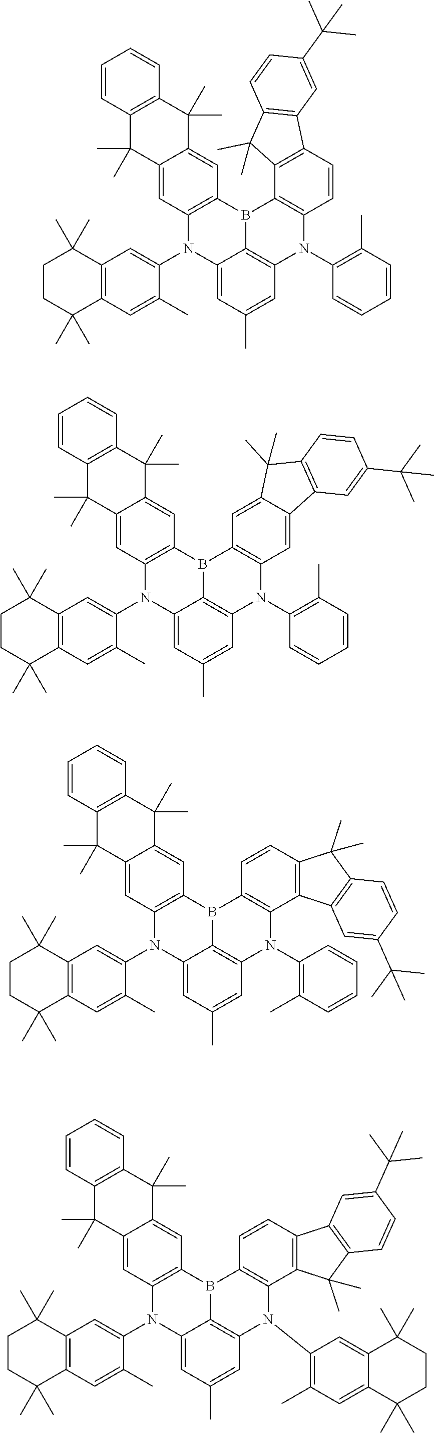

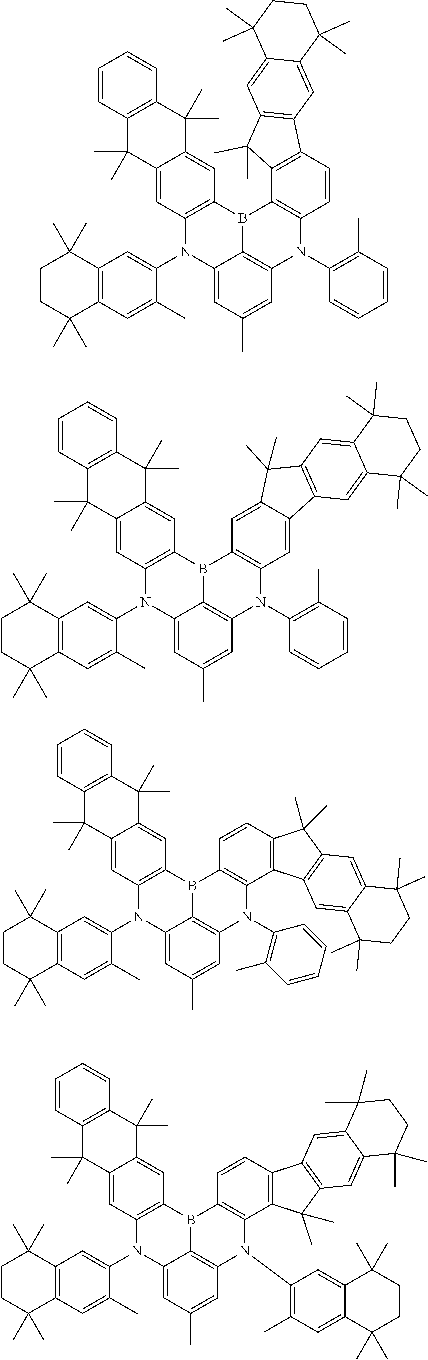

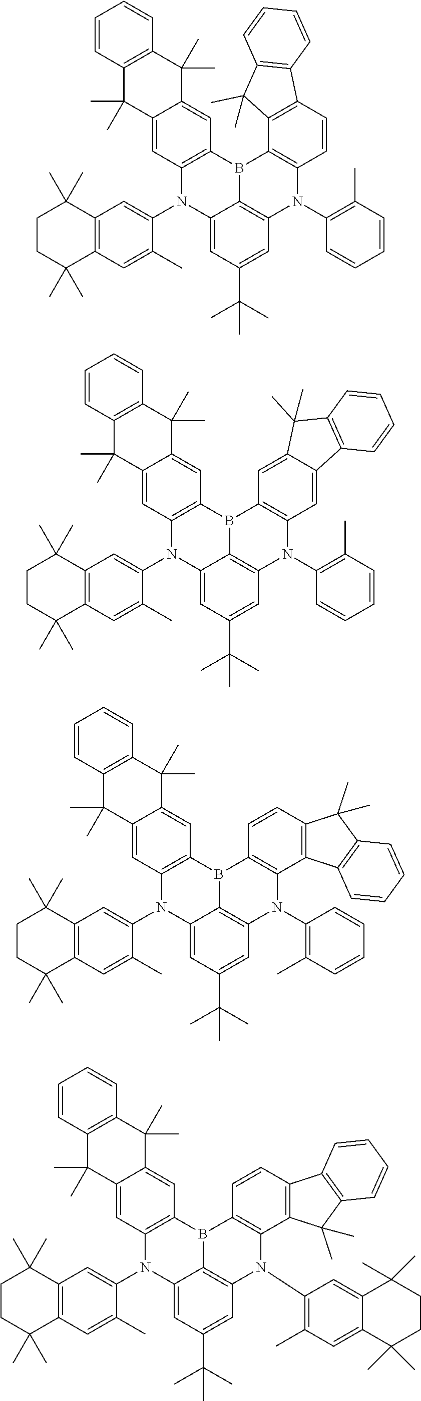

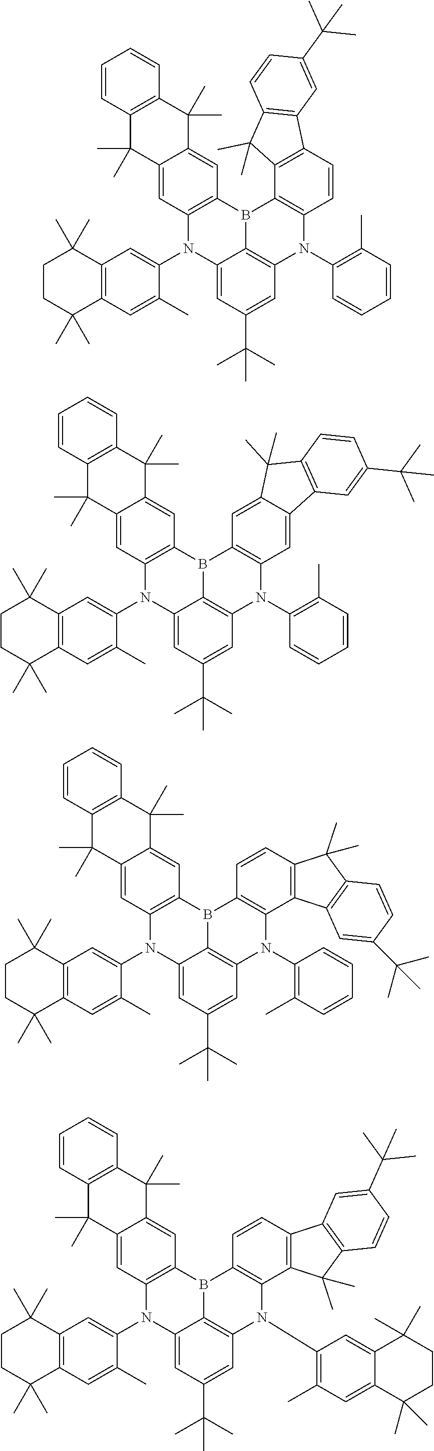

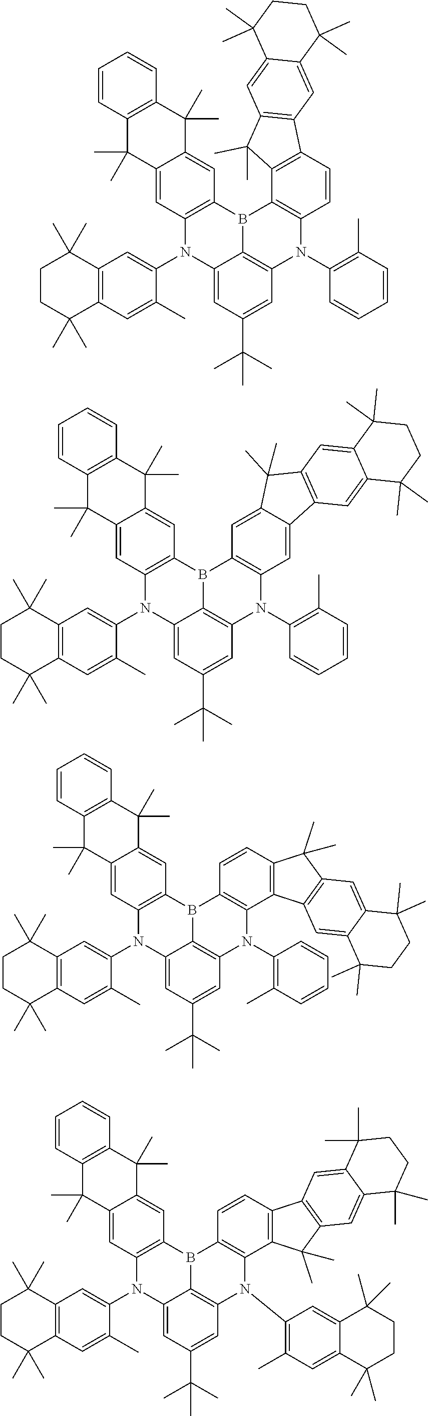

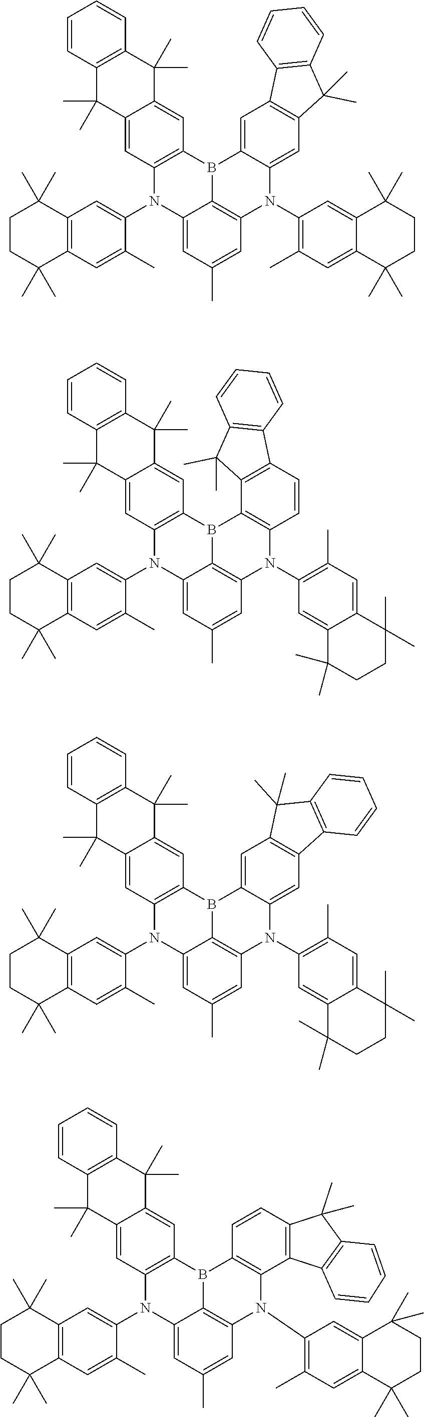

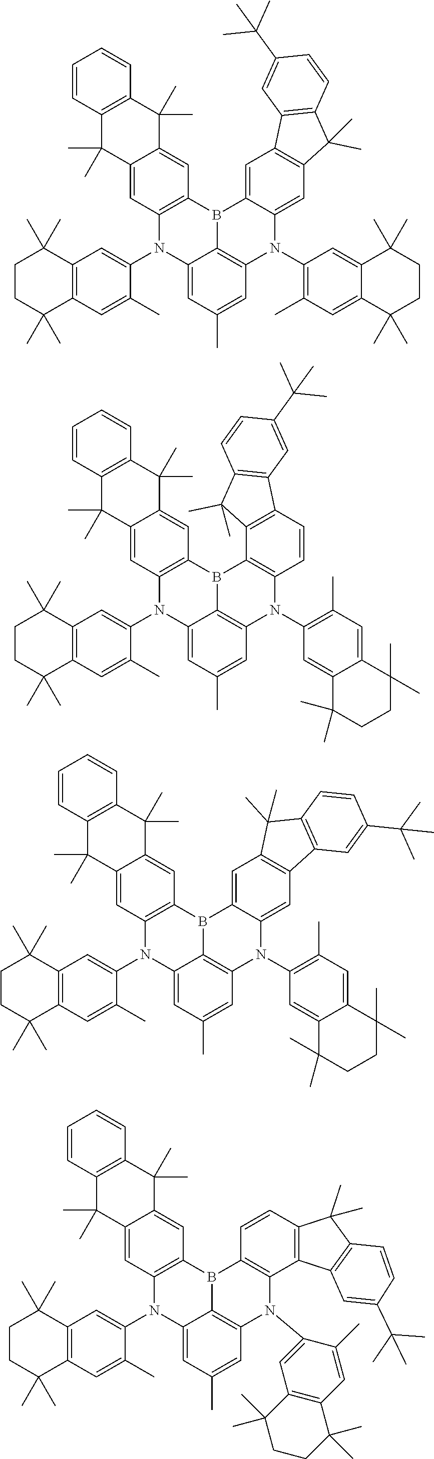

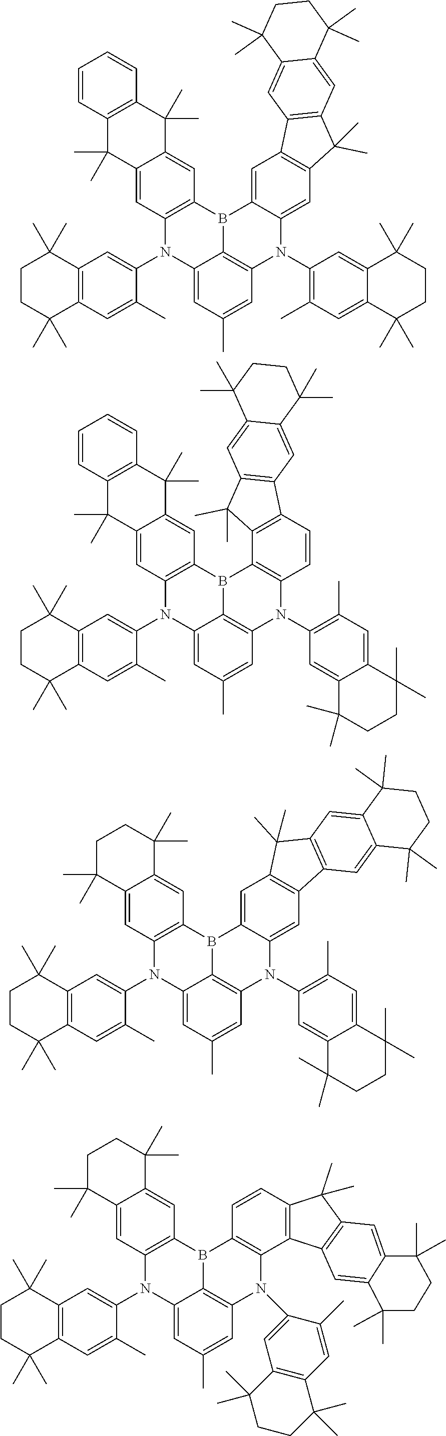

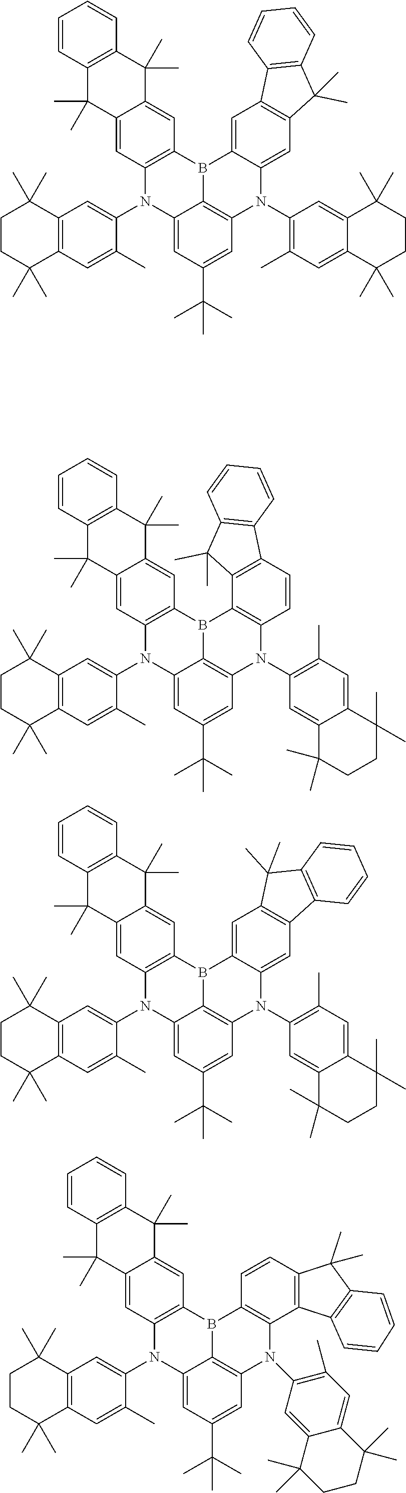

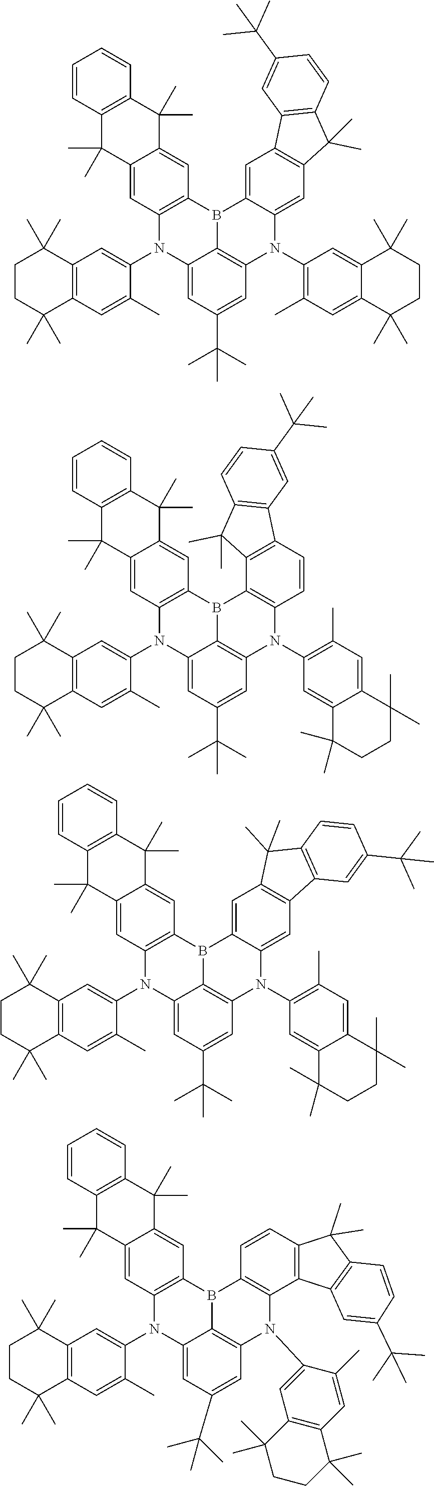

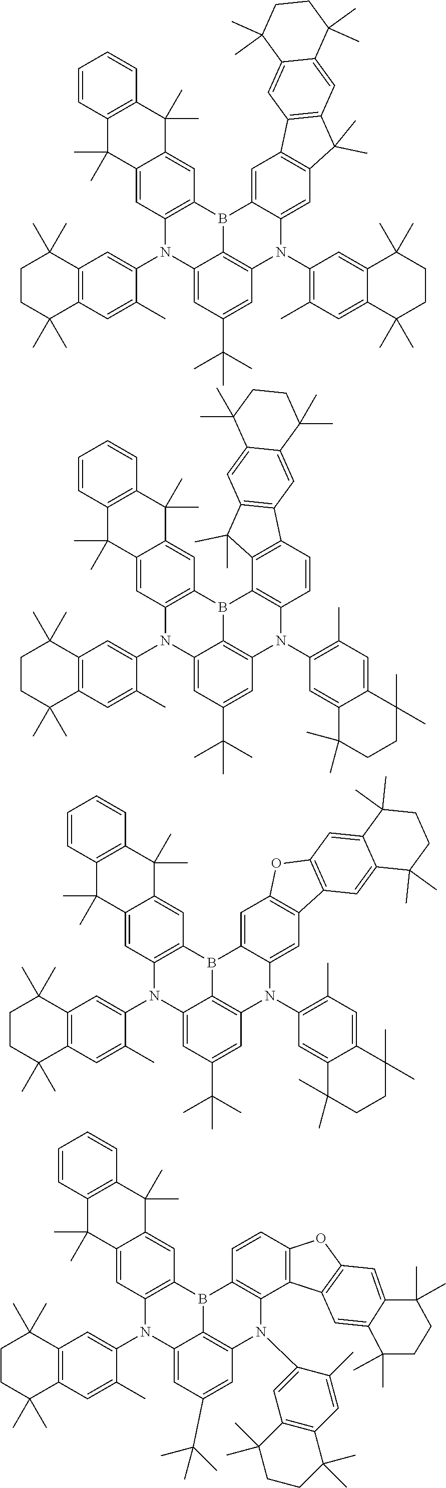

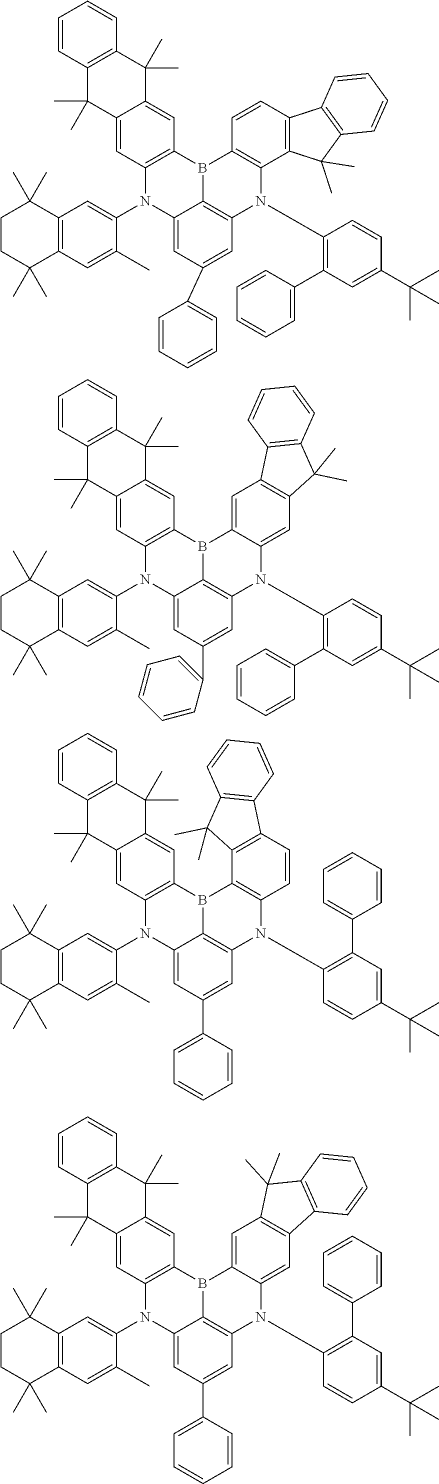

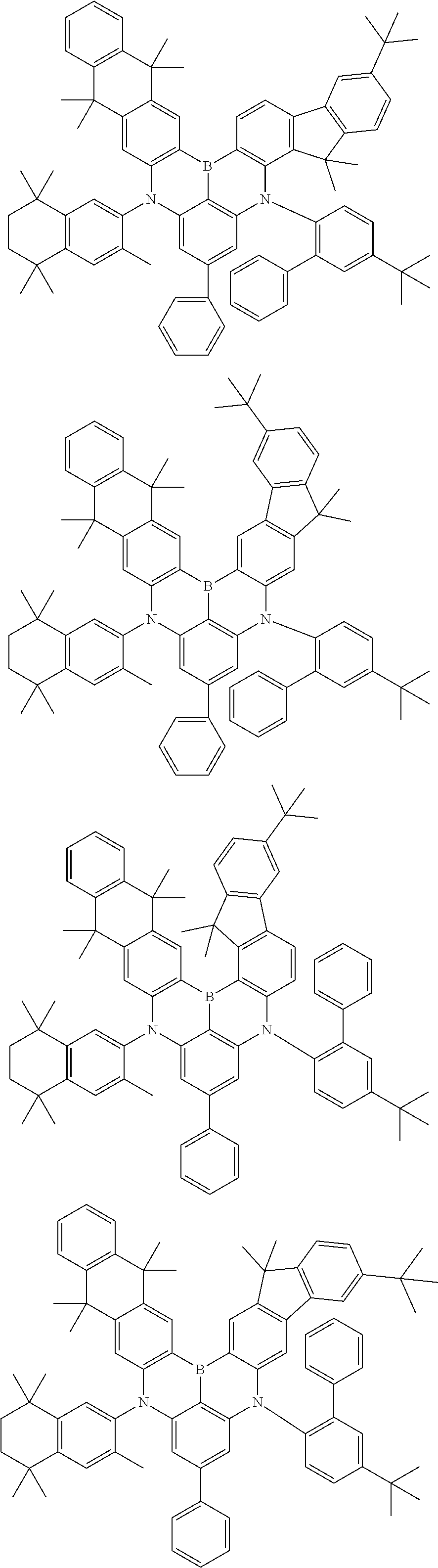

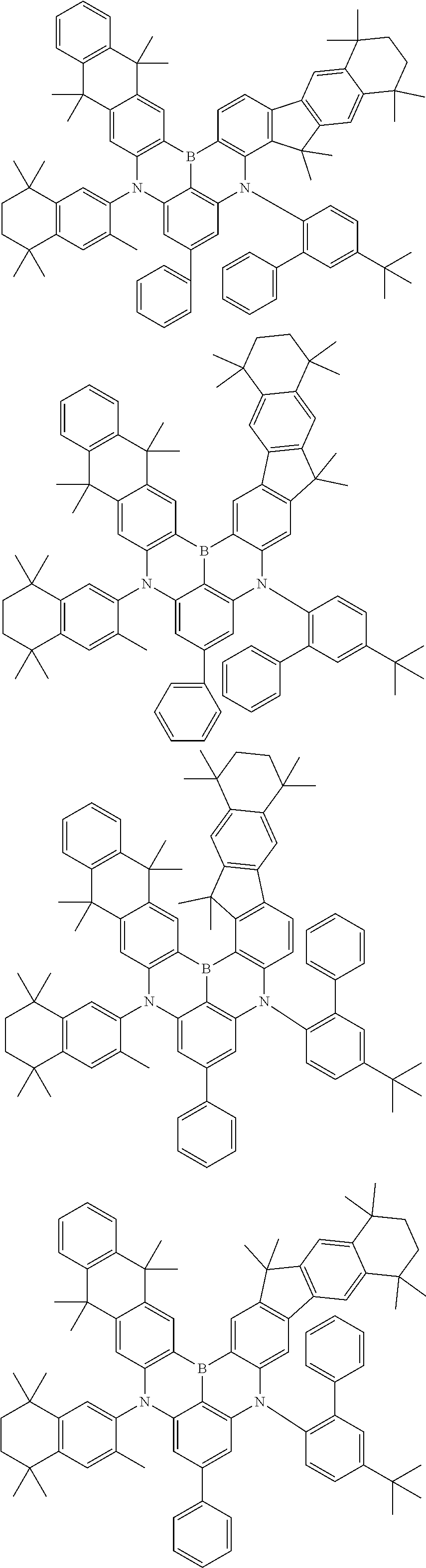

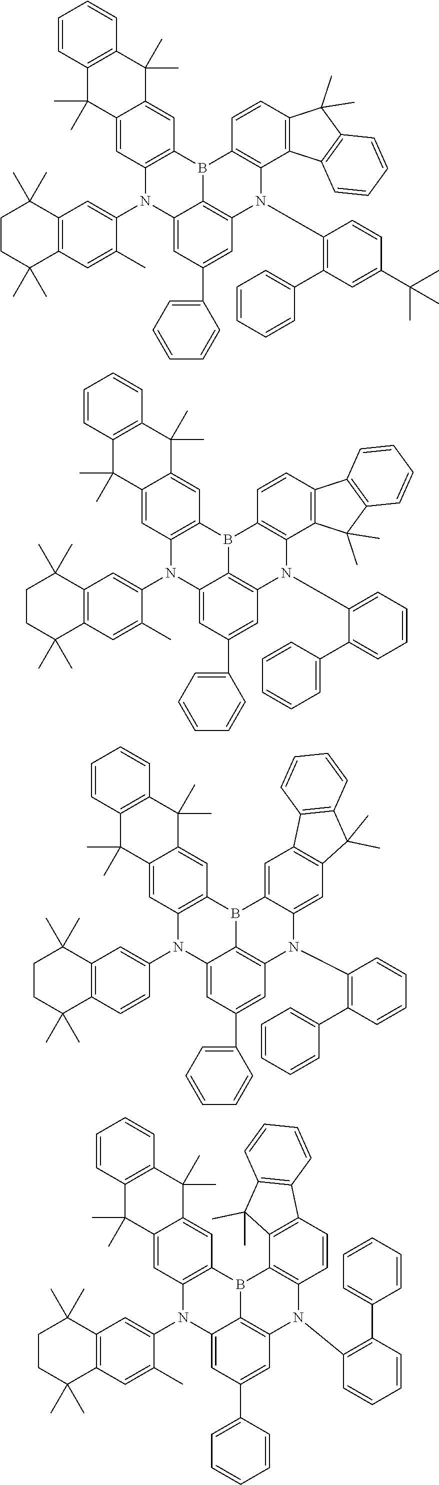

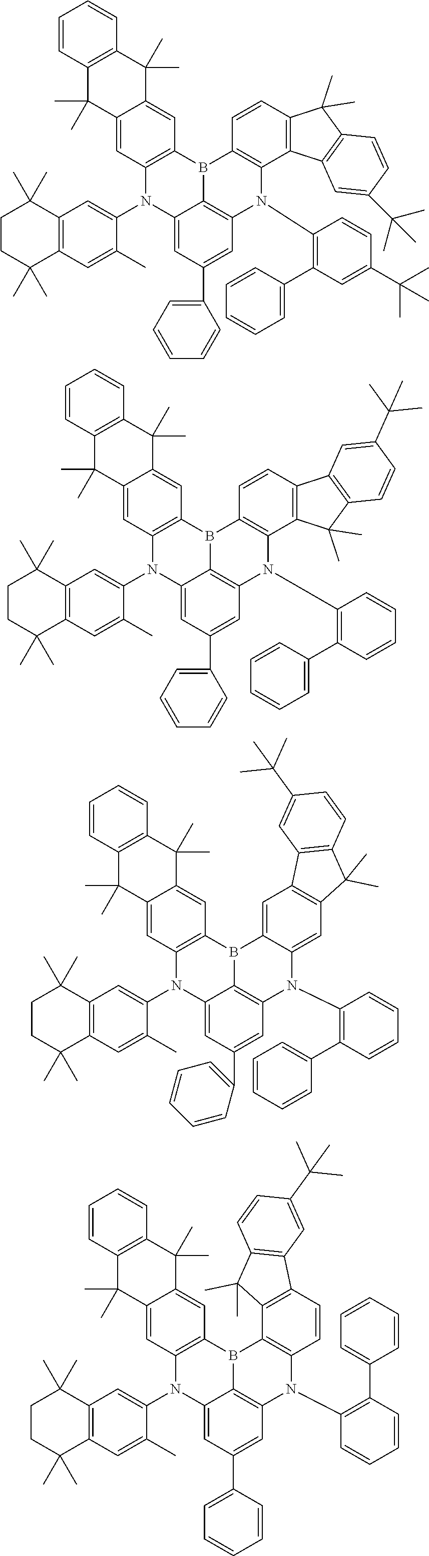

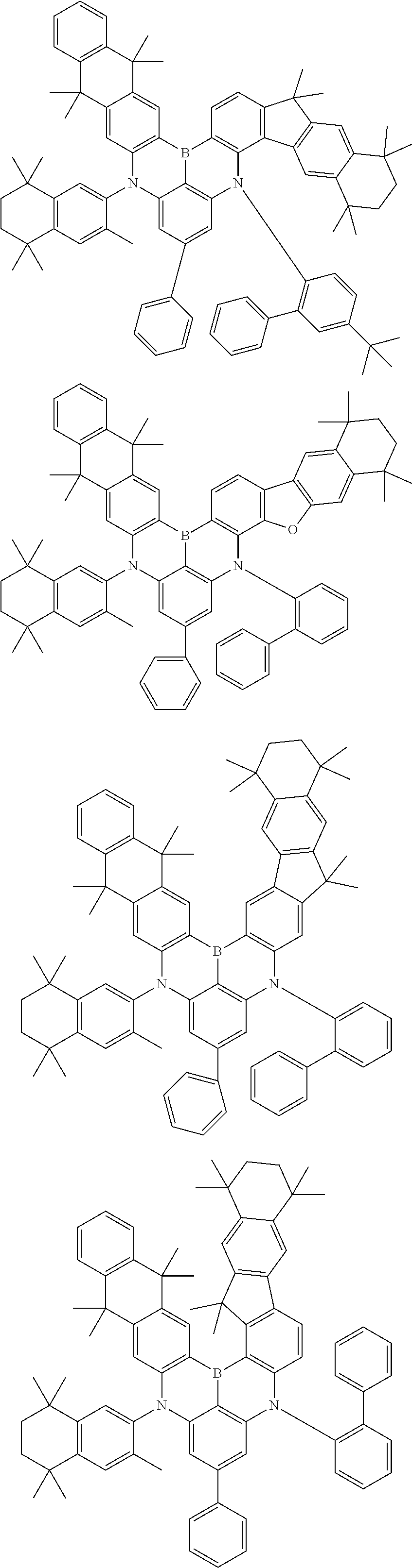

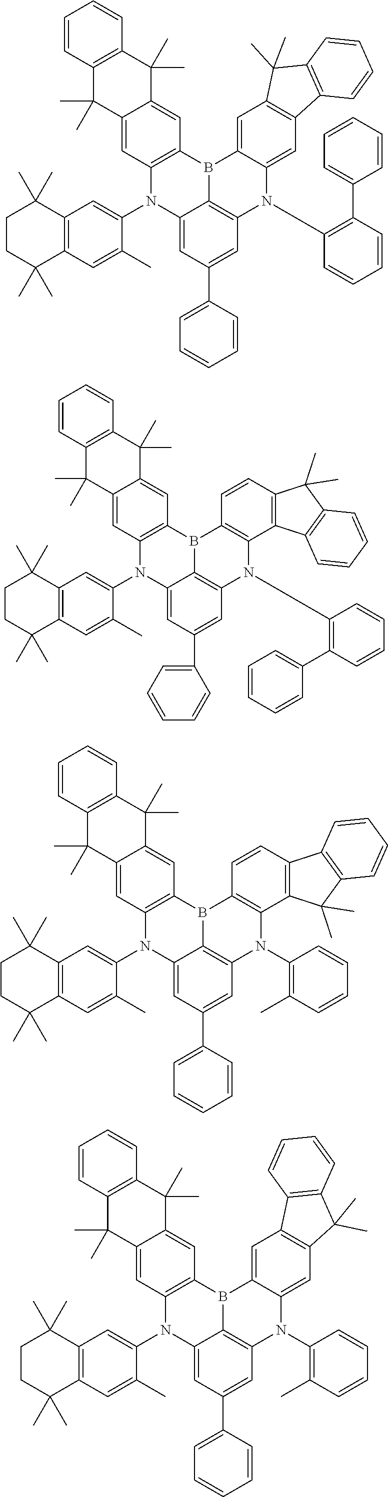

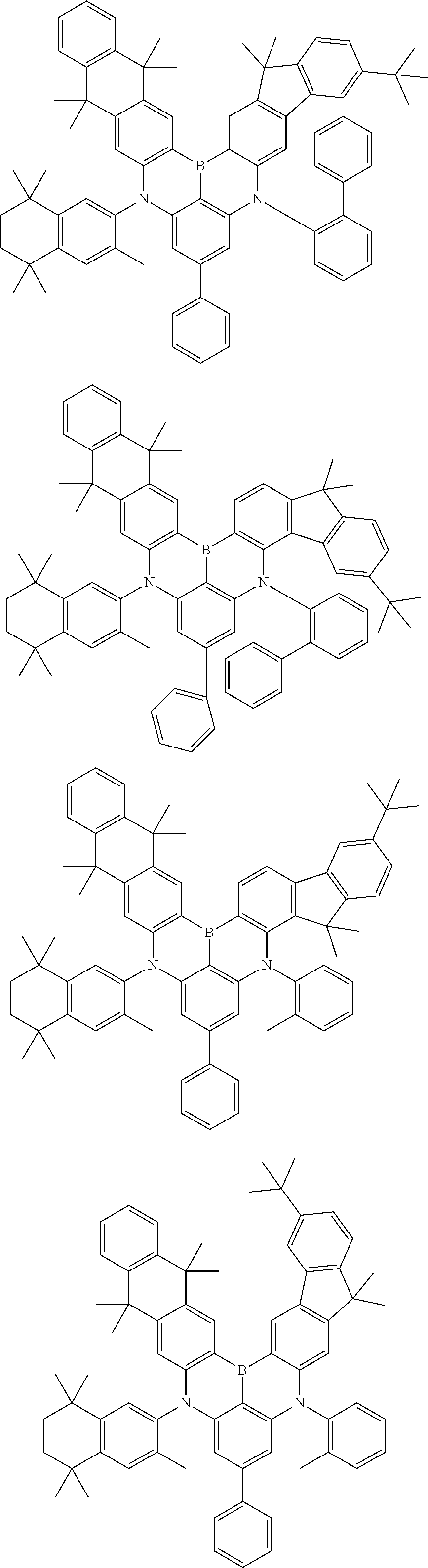

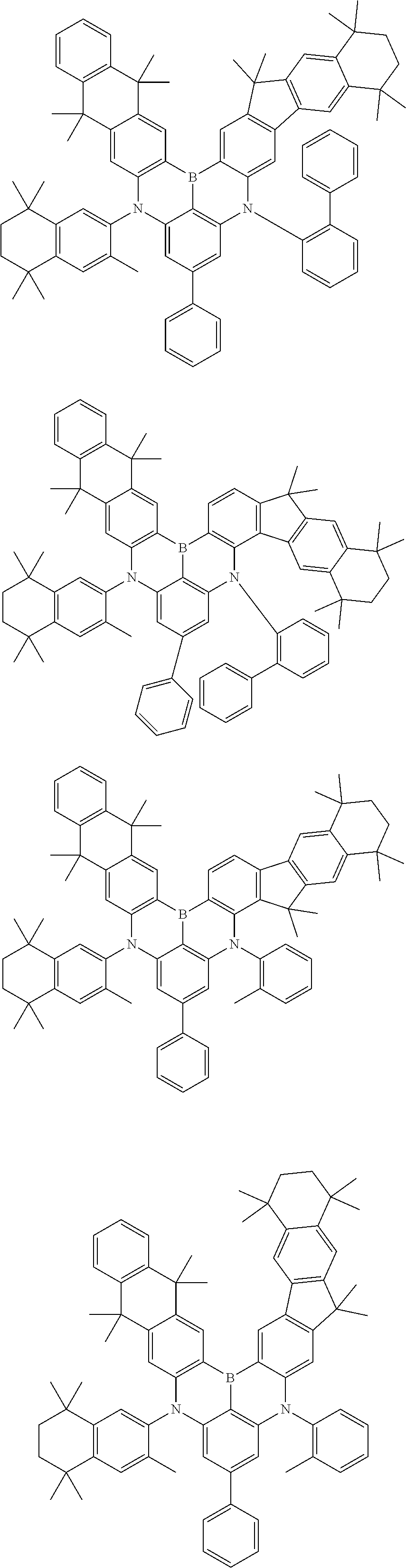

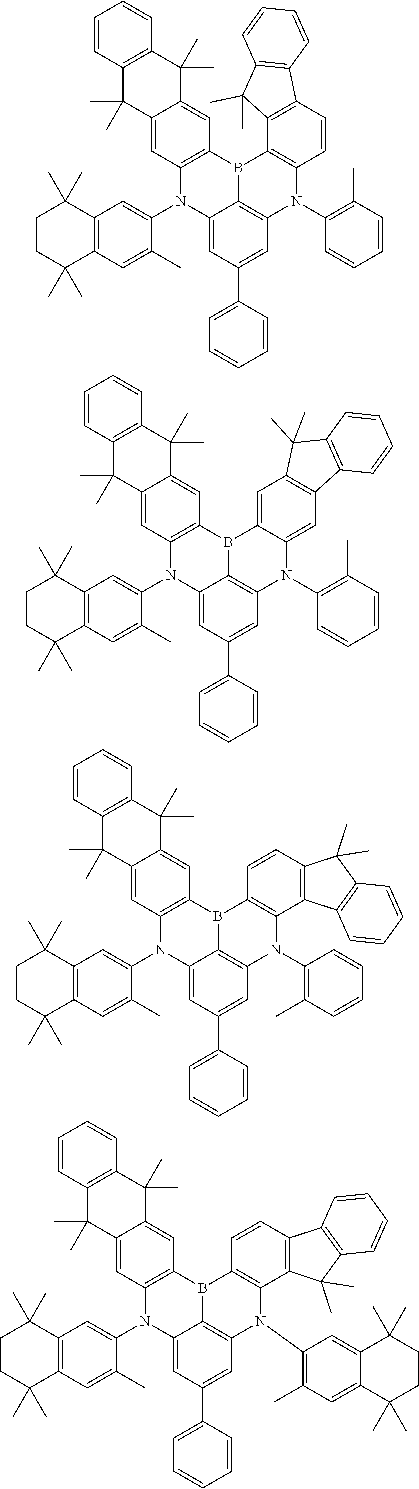

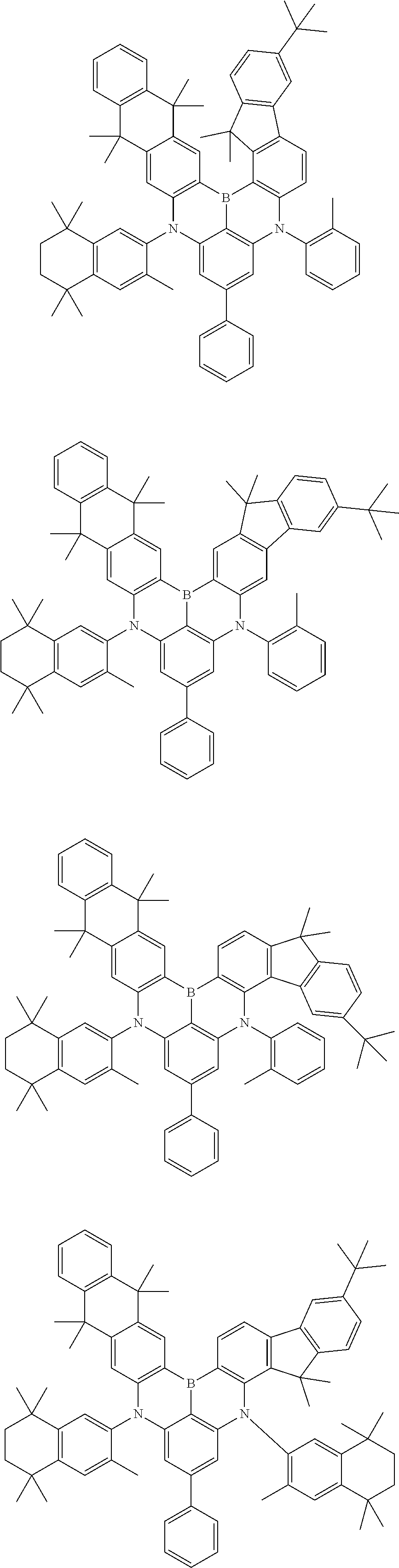

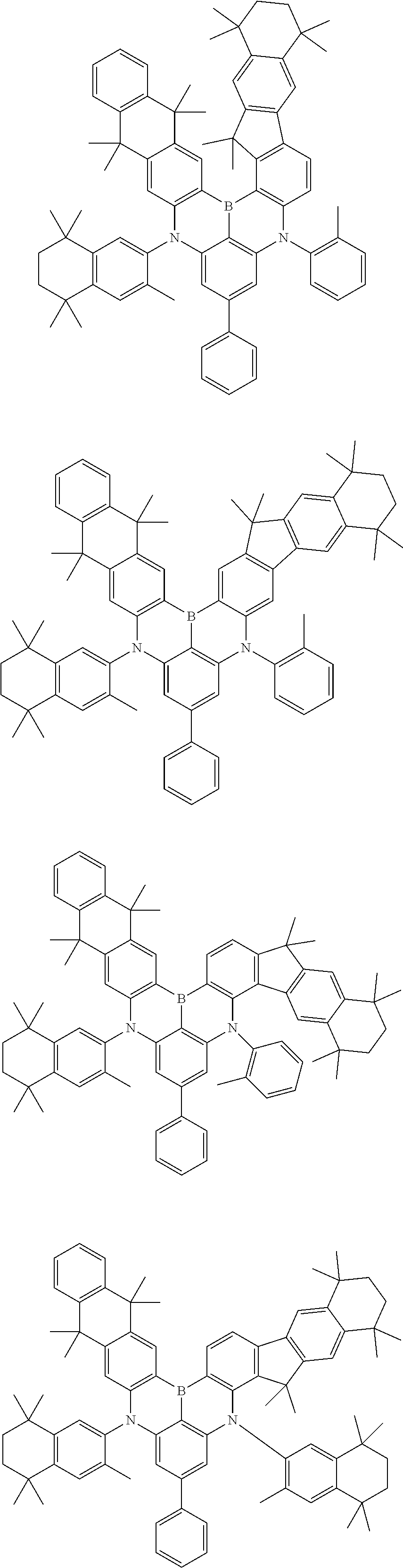

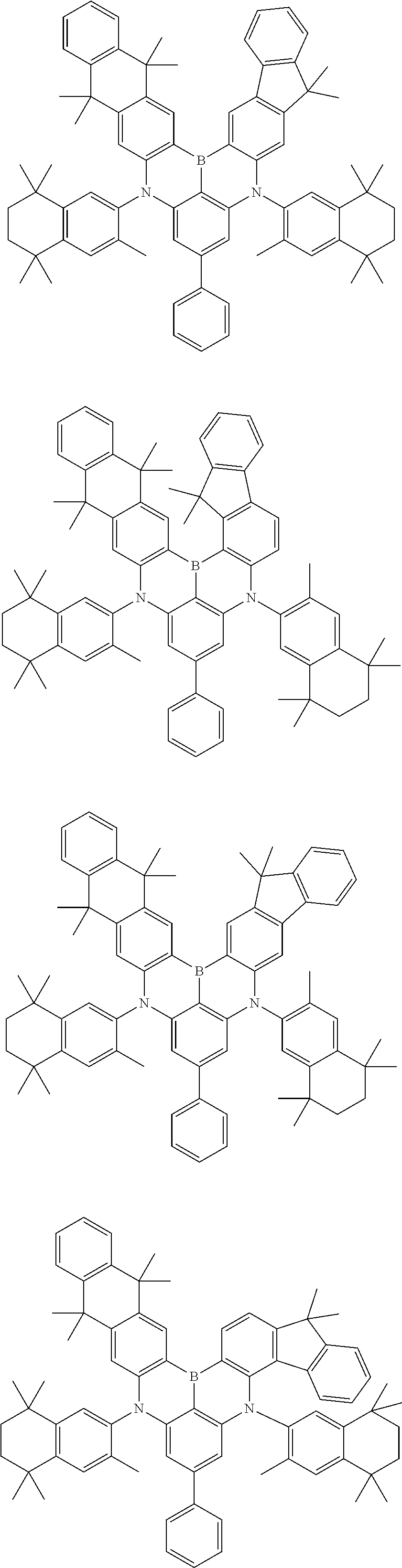

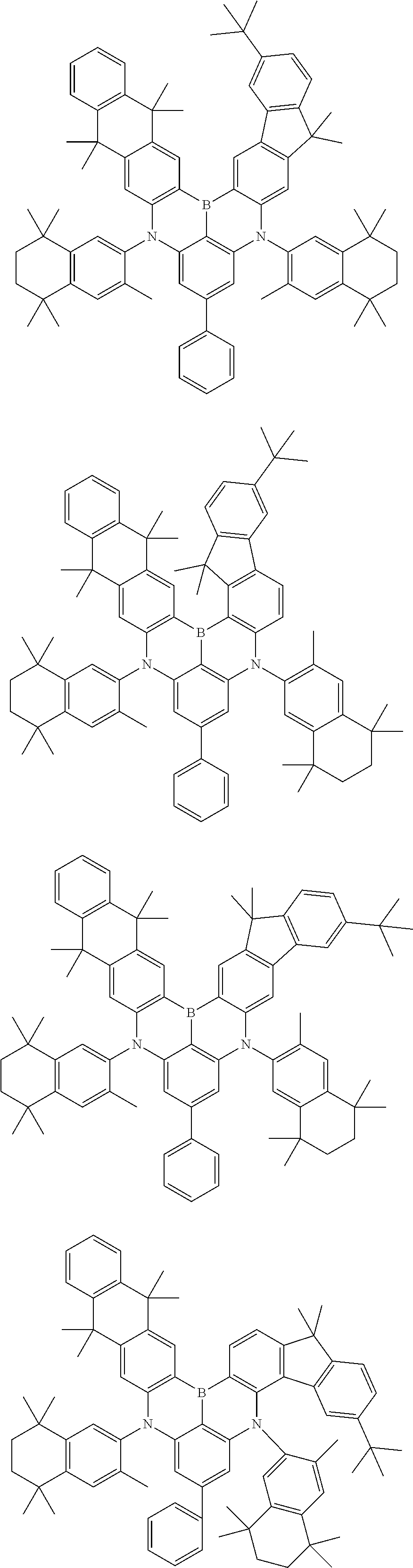

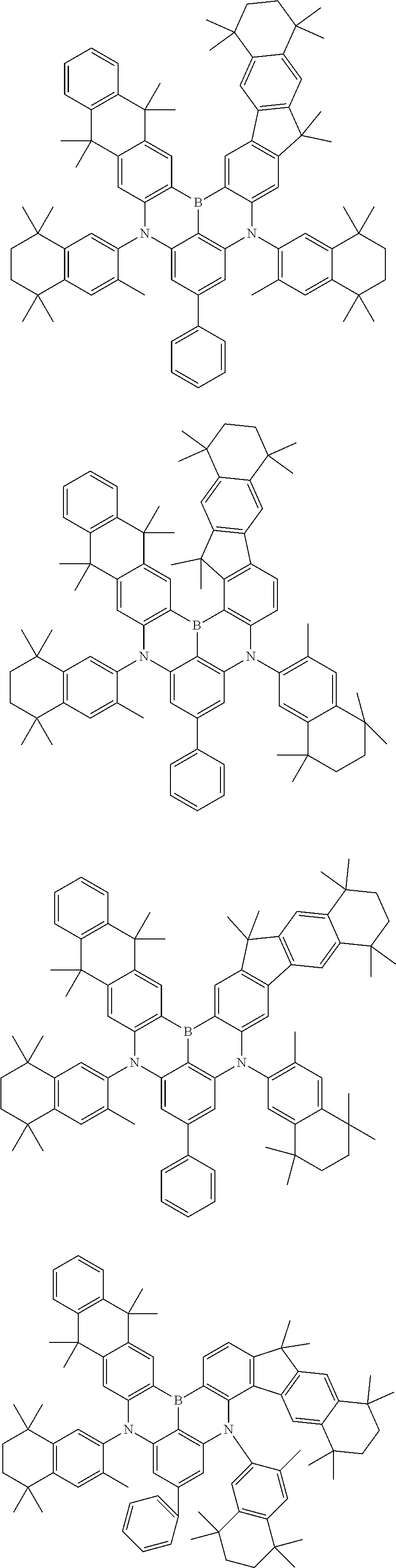

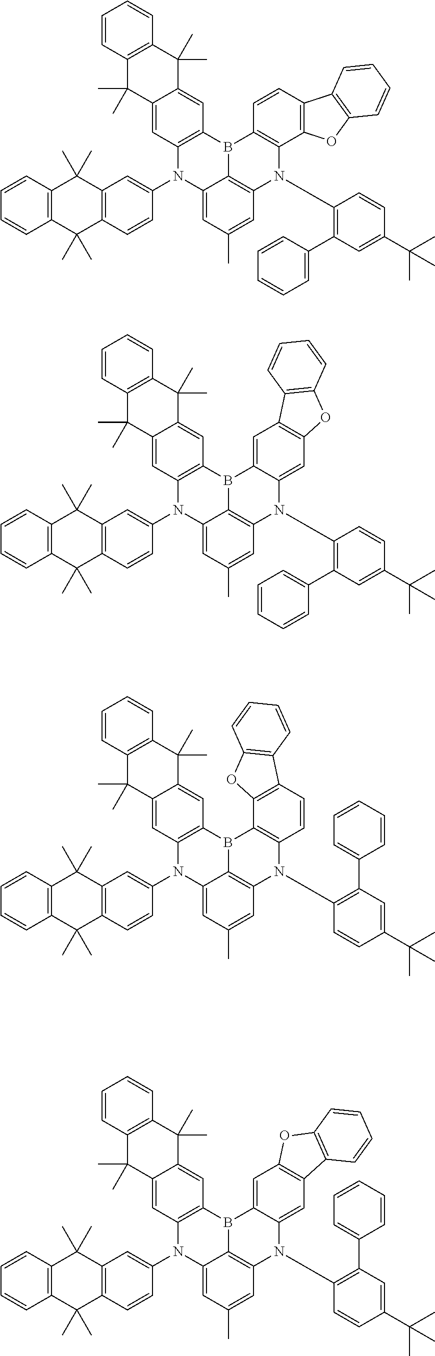

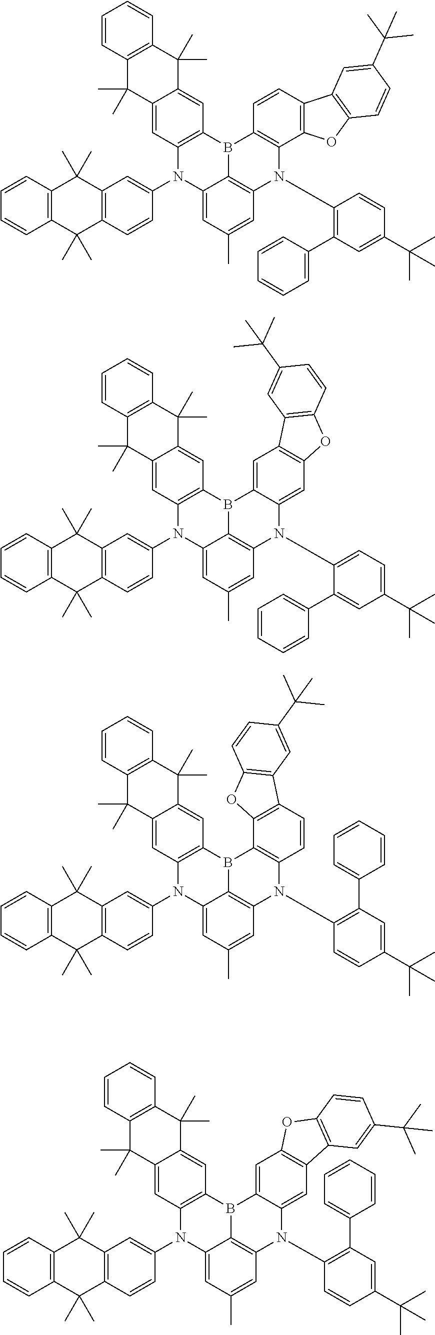

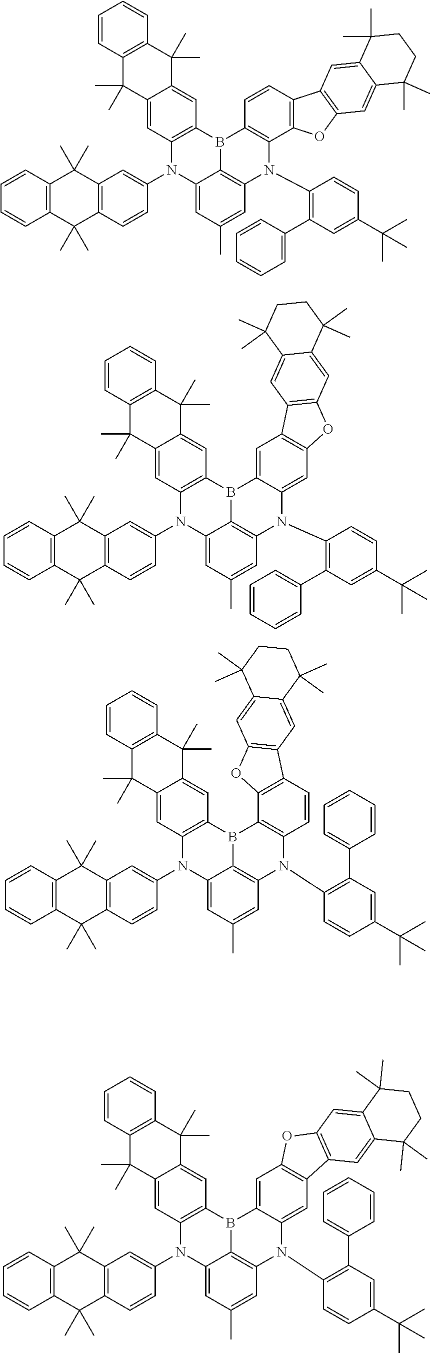

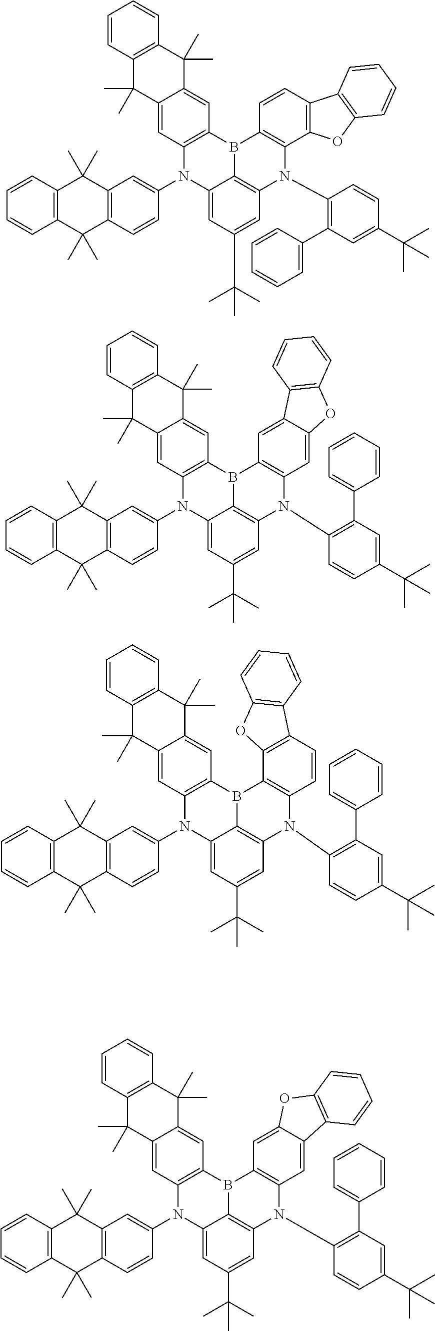

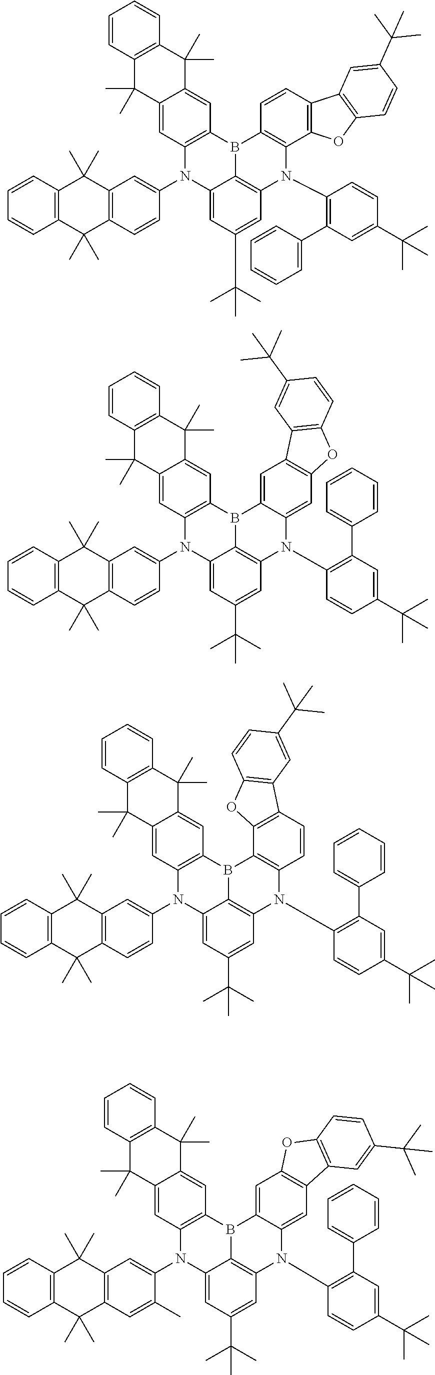

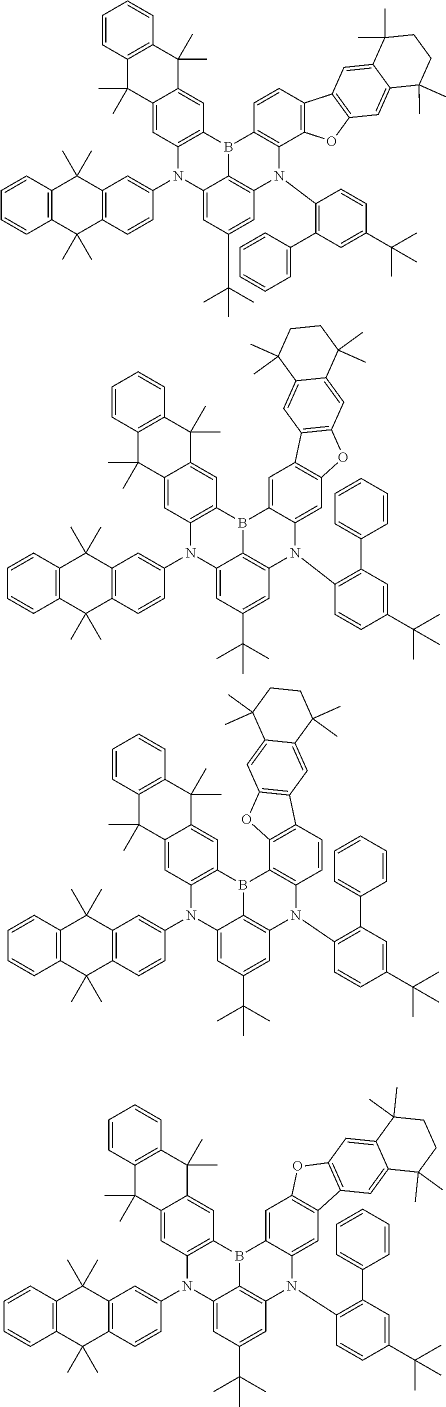

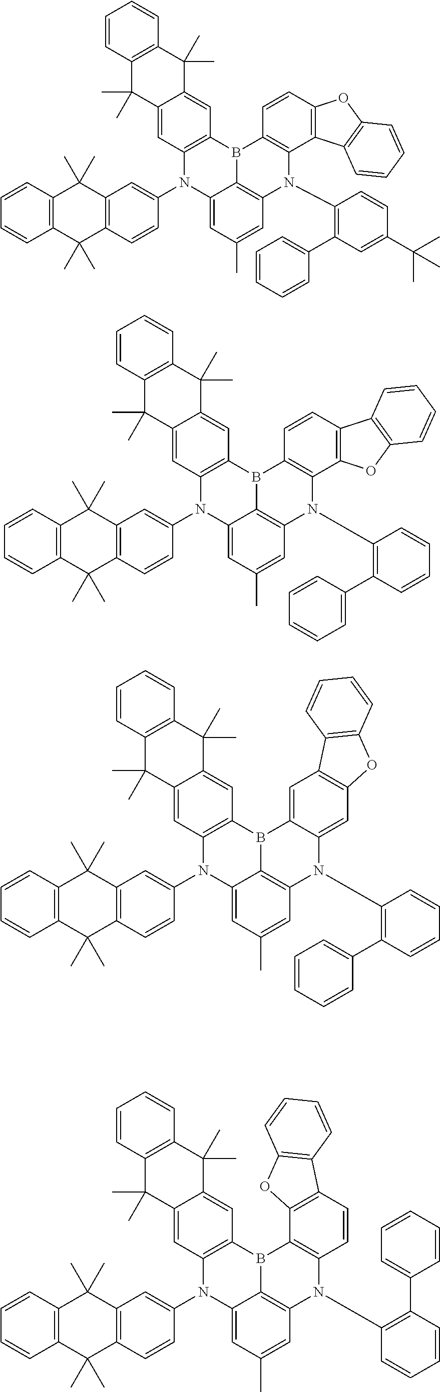

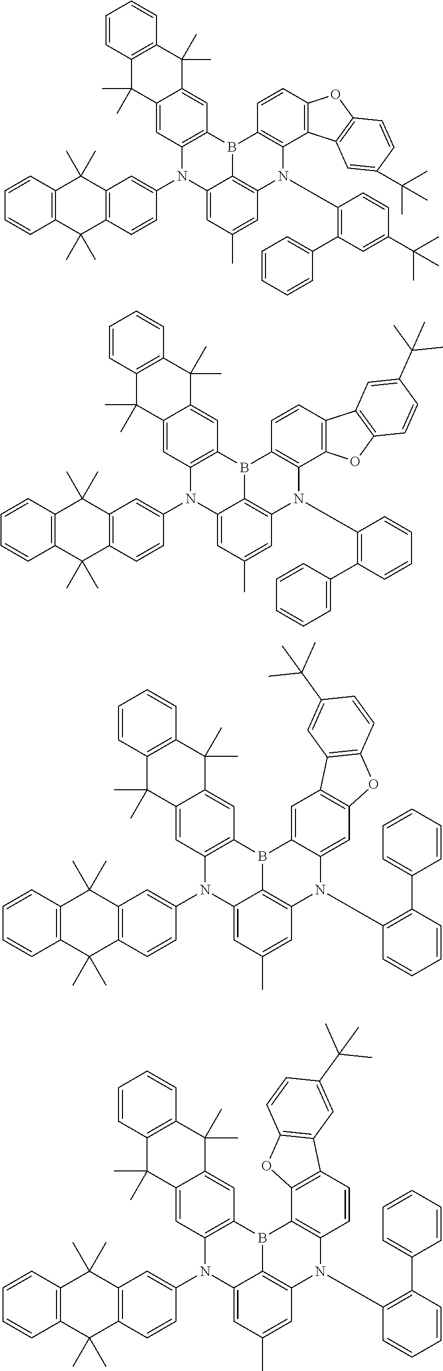

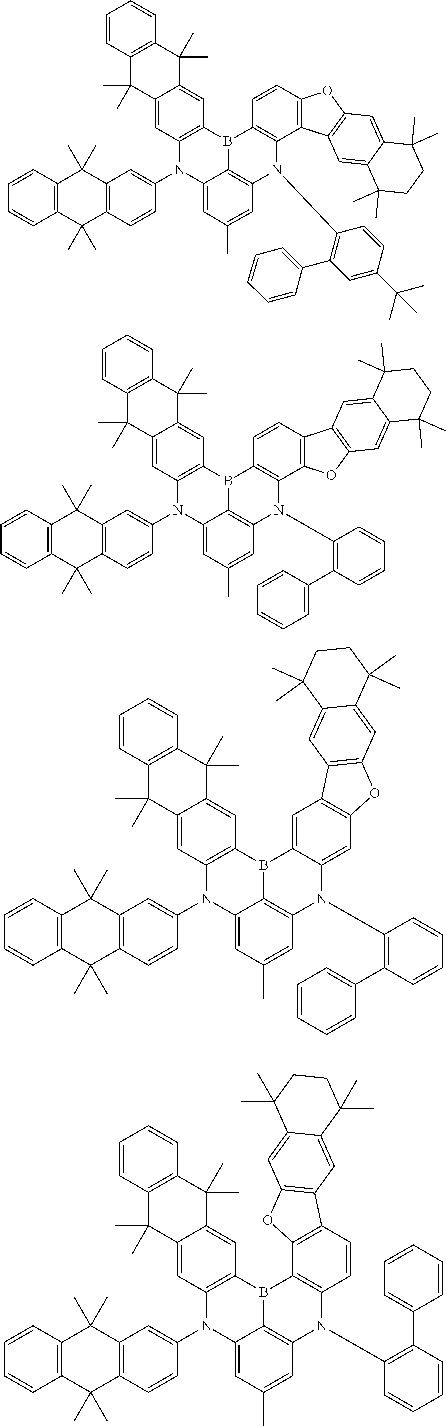

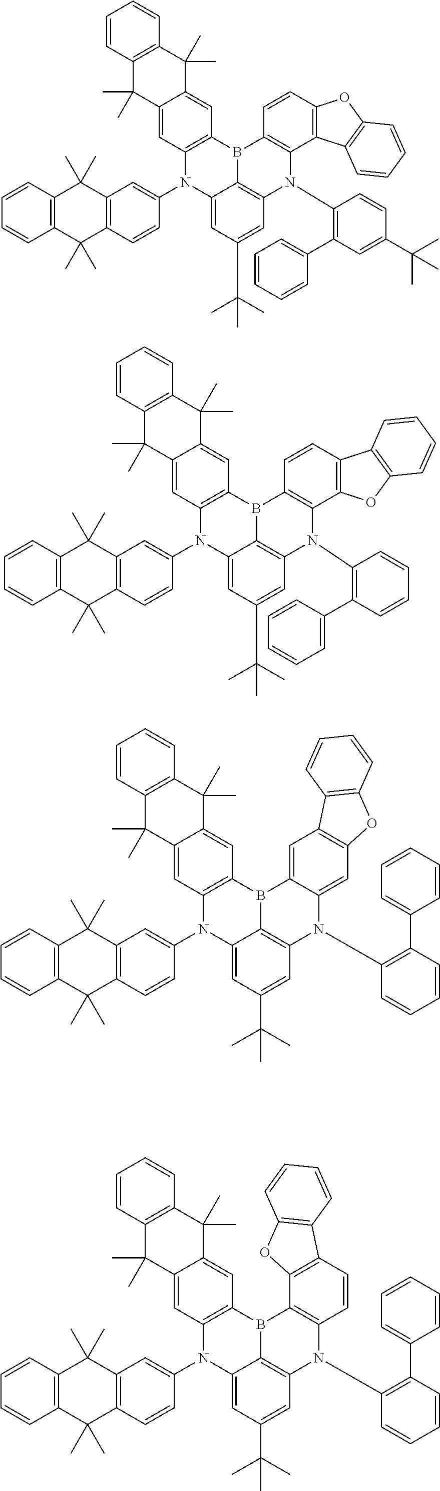

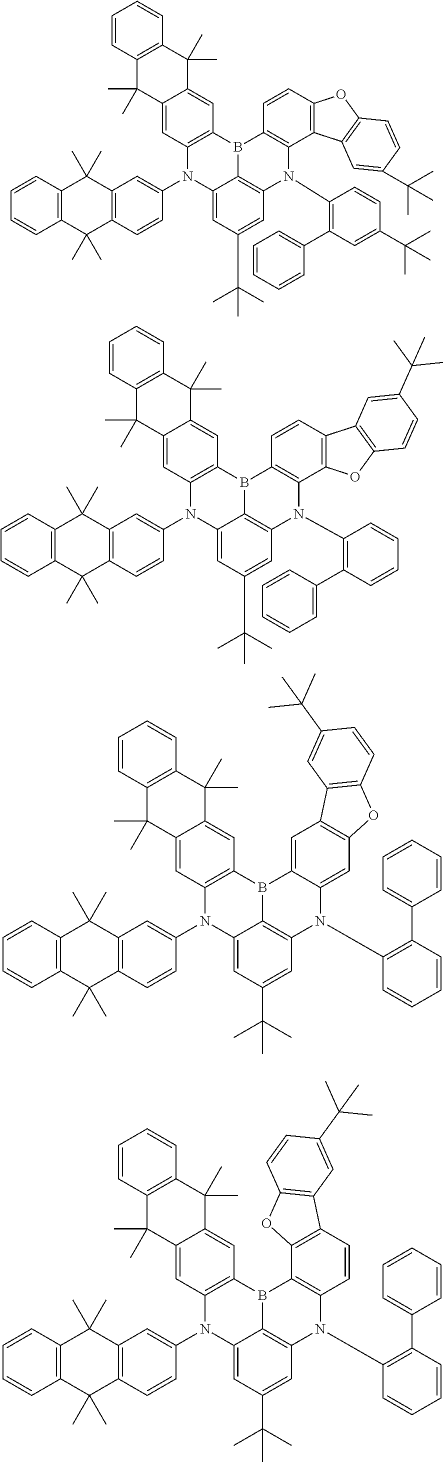

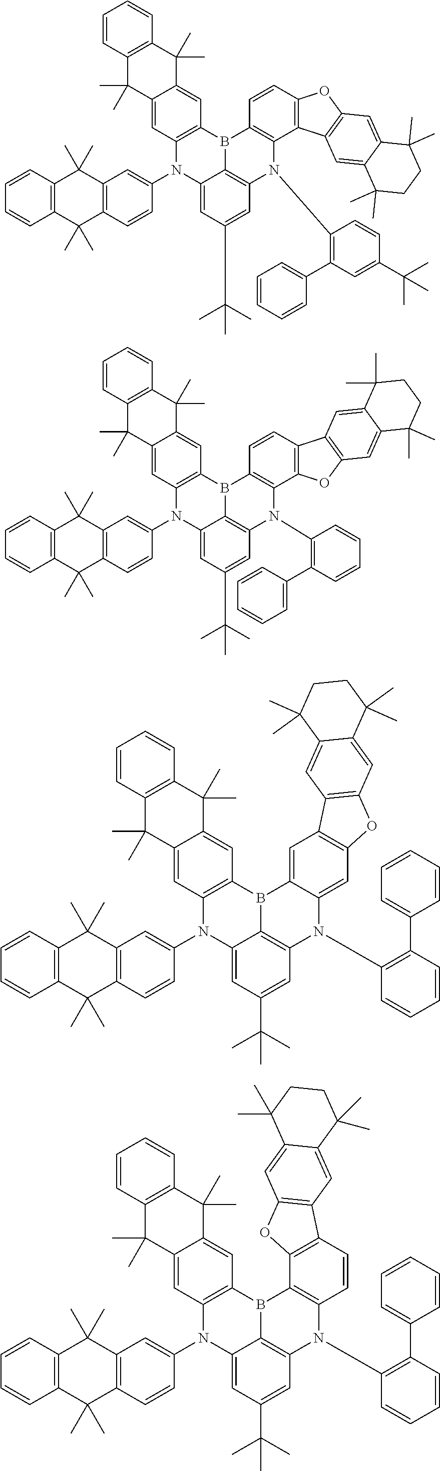

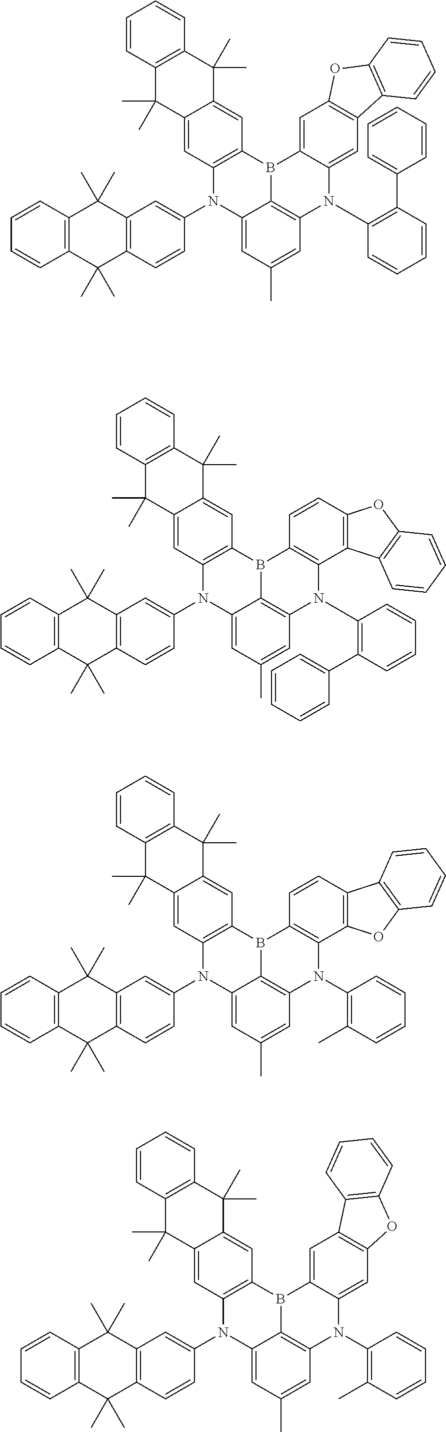 [SMILES: Cc1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)oc1ccccc14 ; Cc1cc2c3c(c1)N(c1ccccc1-c1ccccc1)c1c(ccc4oc5ccccc5c14)B3c1cc3c(cc1N2c1ccc2c(c1)C(C)(C)c1ccccc1C2(C)C)C(C)(C)c1ccccc1C3(C)C ; Cc1cc2c3c(c1)N(c1ccccc1C)c1c(ccc4c1oc1ccccc14)B3c1cc3c(cc1N2c1ccc2c(c1)C(C)(C)c1ccccc1C2(C)C)C(C)(C)c1ccccc1C3(C)C ; Cc1cc2c3c(c1)N(c1ccccc1C)c1cc4oc5ccccc5c4cc1B3c1cc3c(cc1N2c1ccc2c(c1)C(C)(C)c1ccccc1C2(C)C)C(C)(C)c1ccccc1C3(C)C]

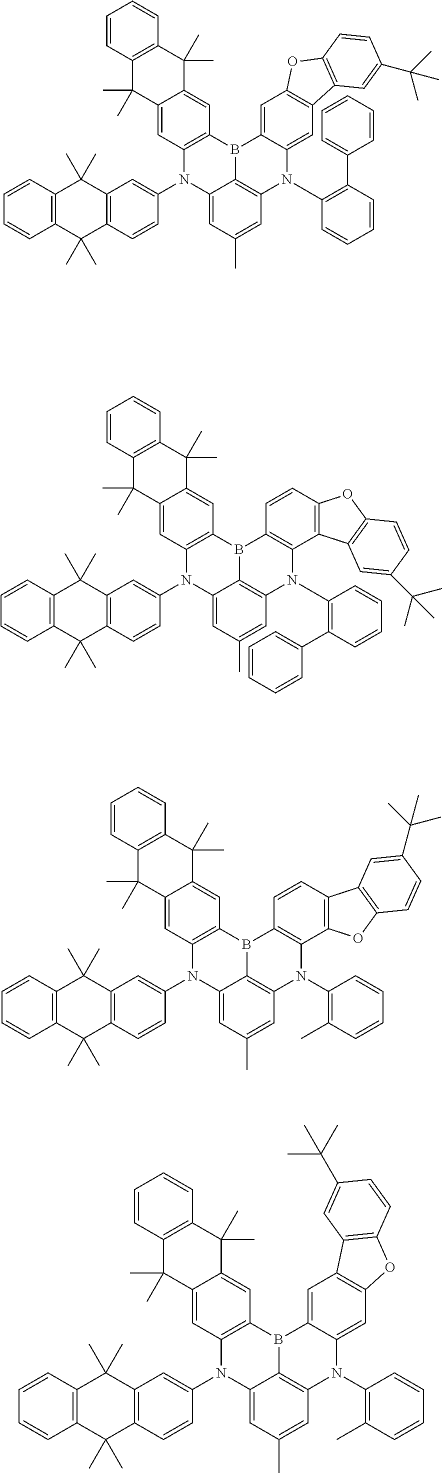

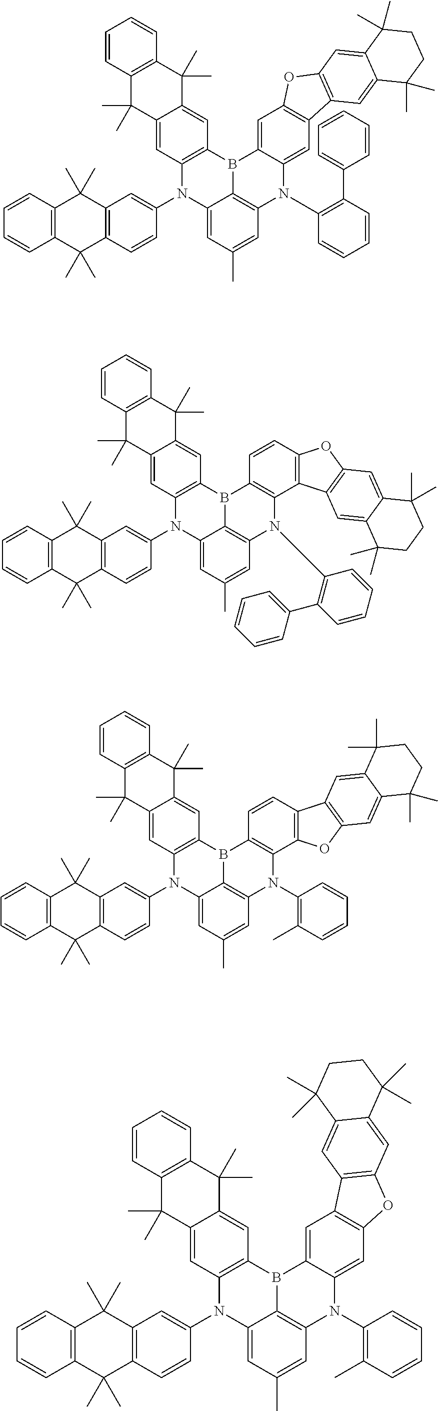

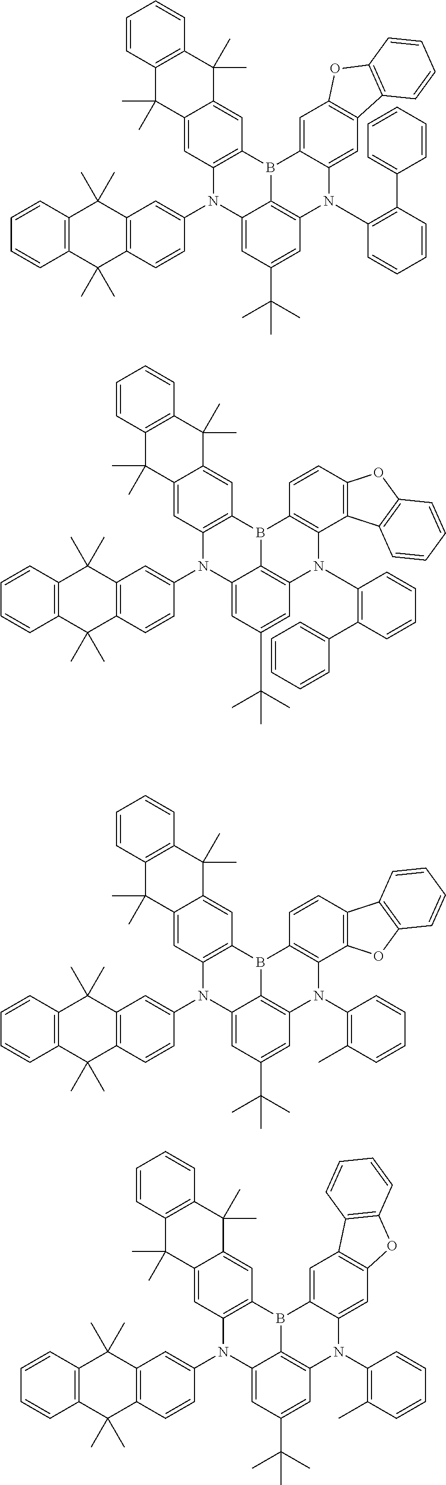

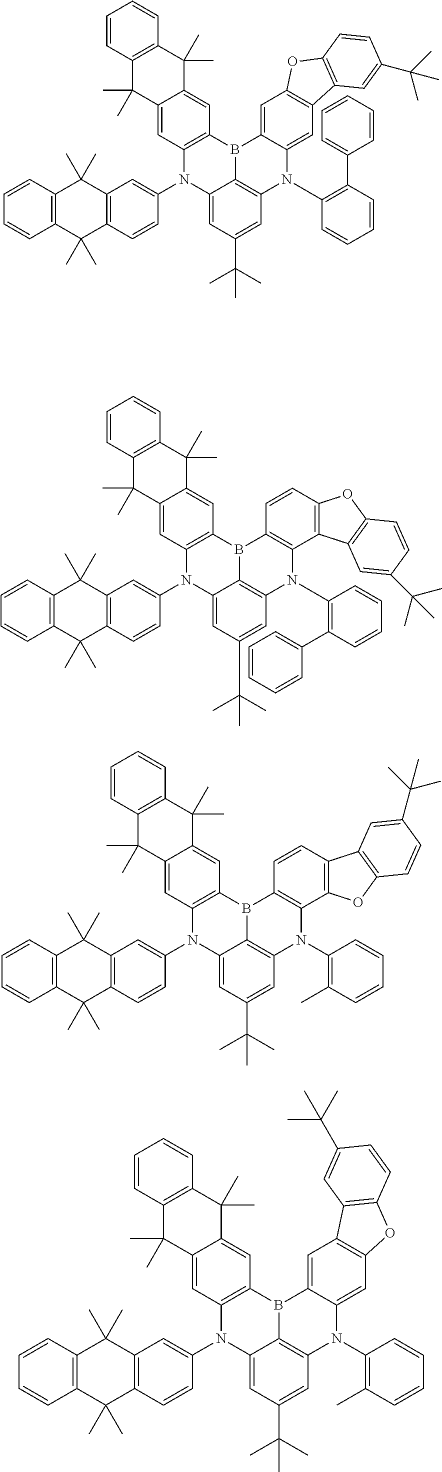

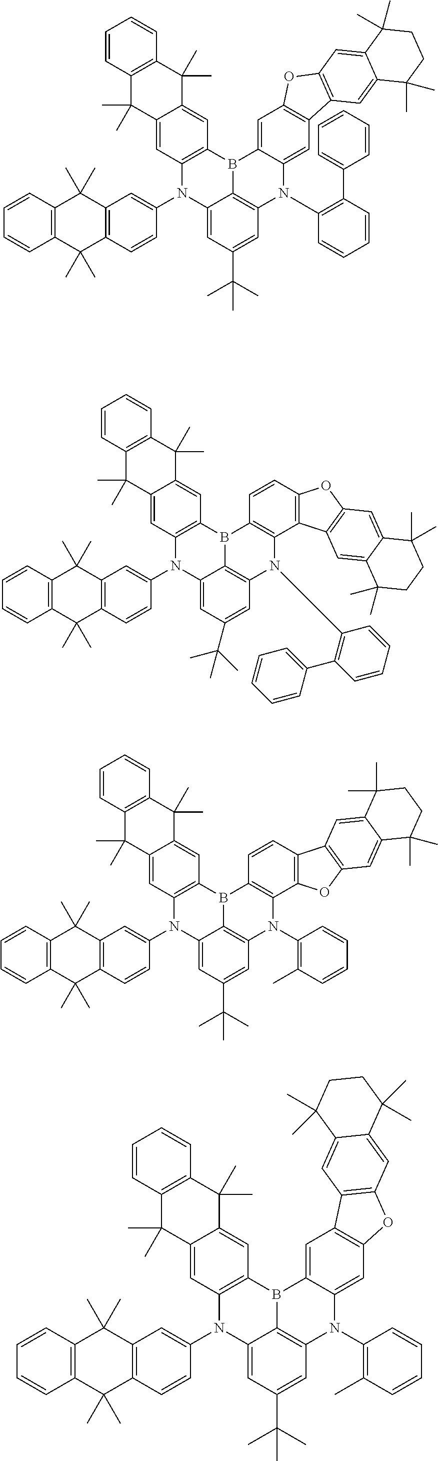

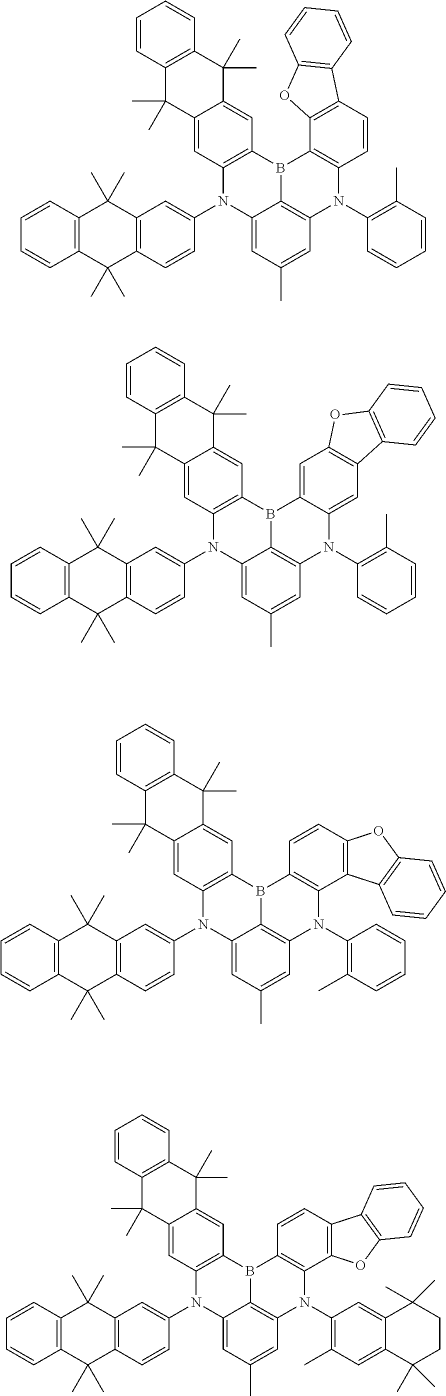 [SMILES: Cc1cc2c3c(c1)N(c1ccccc1C)c1ccc4c(oc5ccccc54)c1B3c1cc3c(cc1N2c1ccc2c(c1)C(C)(C)c1ccccc1C2(C)C)C(C)(C)c1ccccc1C3(C)C ; Cc1cc2c3c(c1)N(c1ccccc1C)c1cc4c(cc1B3c1cc3c(cc1N2c1ccc2c(c1)C(C)(C)c1ccccc1C2(C)C)C(C)(C)c1ccccc1C3(C)C)oc1ccccc14 ; Cc1cc2c3c(c1)N(c1ccccc1C)c1c(ccc4oc5ccccc5c14)B3c1cc3c(cc1N2c1ccc2c(c1)C(C)(C)c1ccccc1C2(C)C)C(C)(C)c1ccccc1C3(C)C ; Cc1cc2c3c(c1)N(c1cc4c(cc1C)C(C)(C)CCC4(C)C)c1c(ccc4c1oc1ccccc14)B3c1cc3c(cc1N2c1ccc2c(c1)C(C)(C)c1ccccc1C2(C)C)C(C)(C)c1ccccc1C3(C)C]

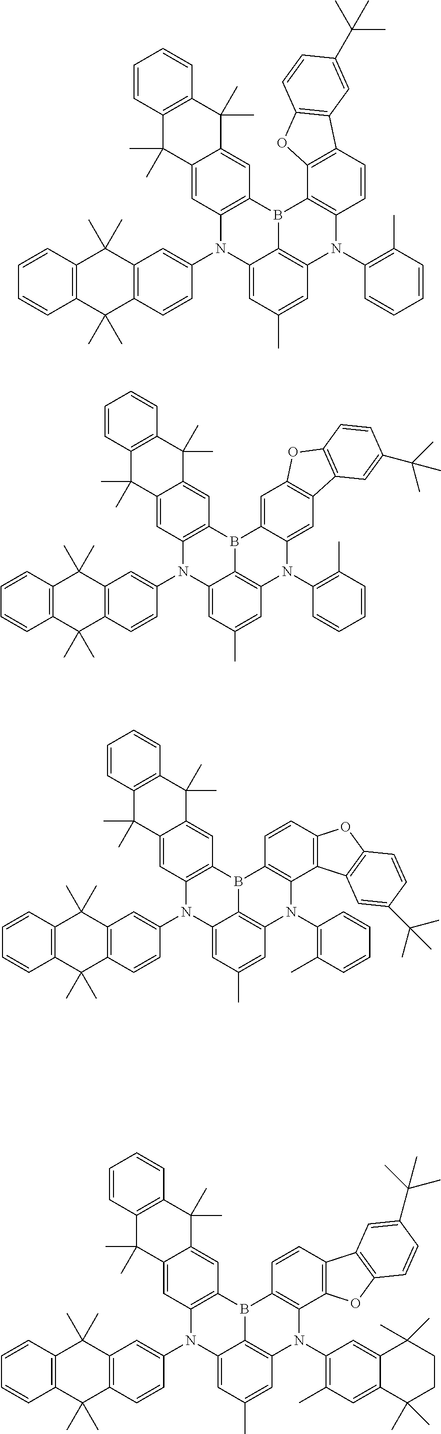

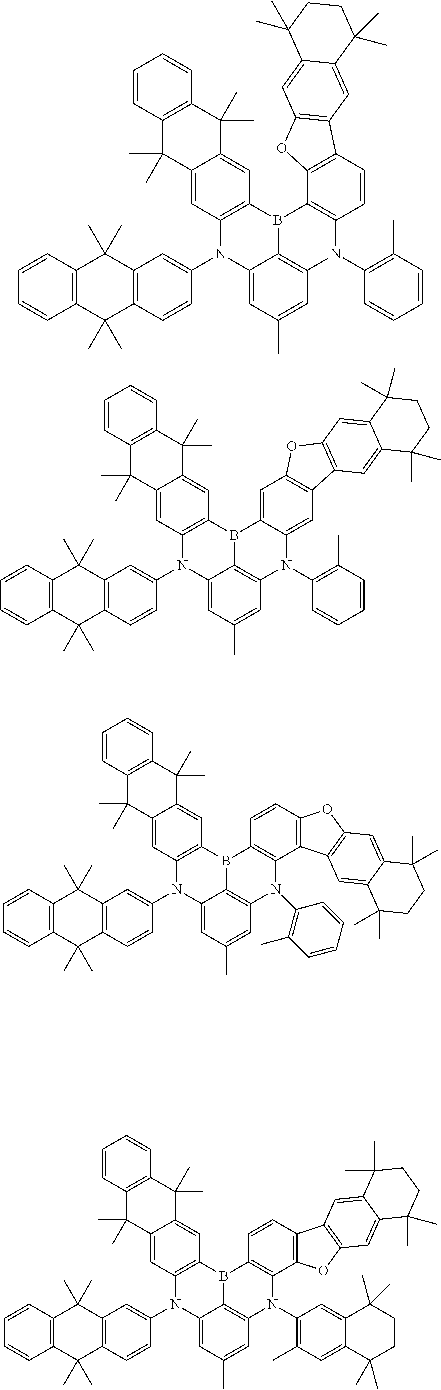

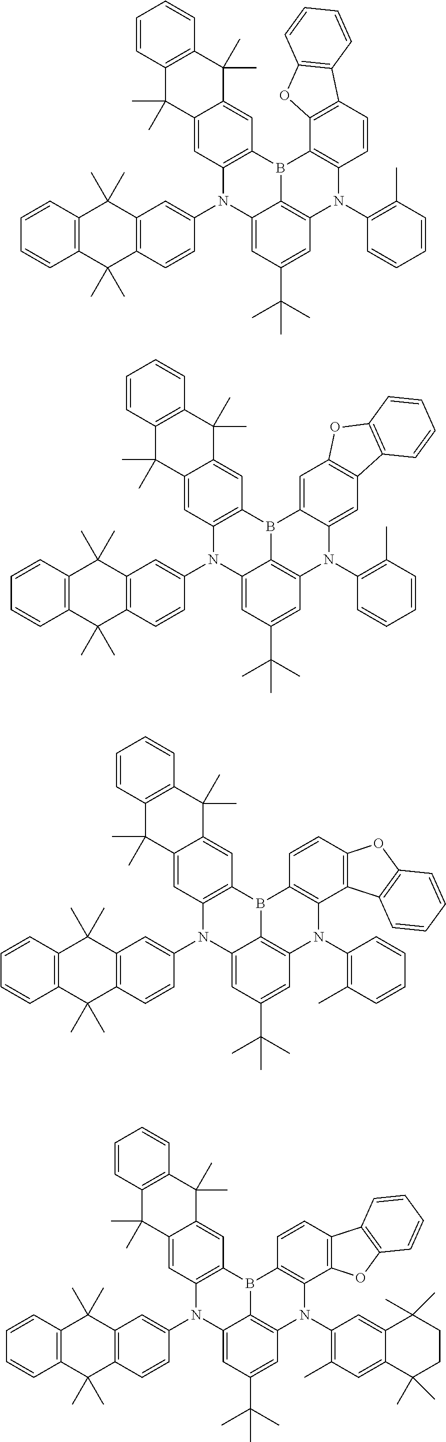

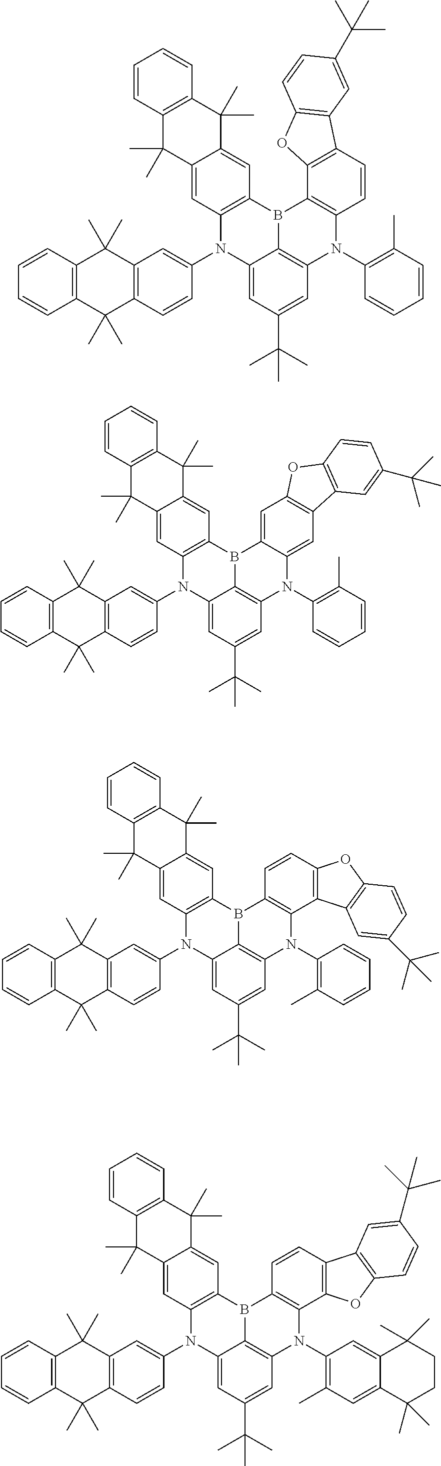

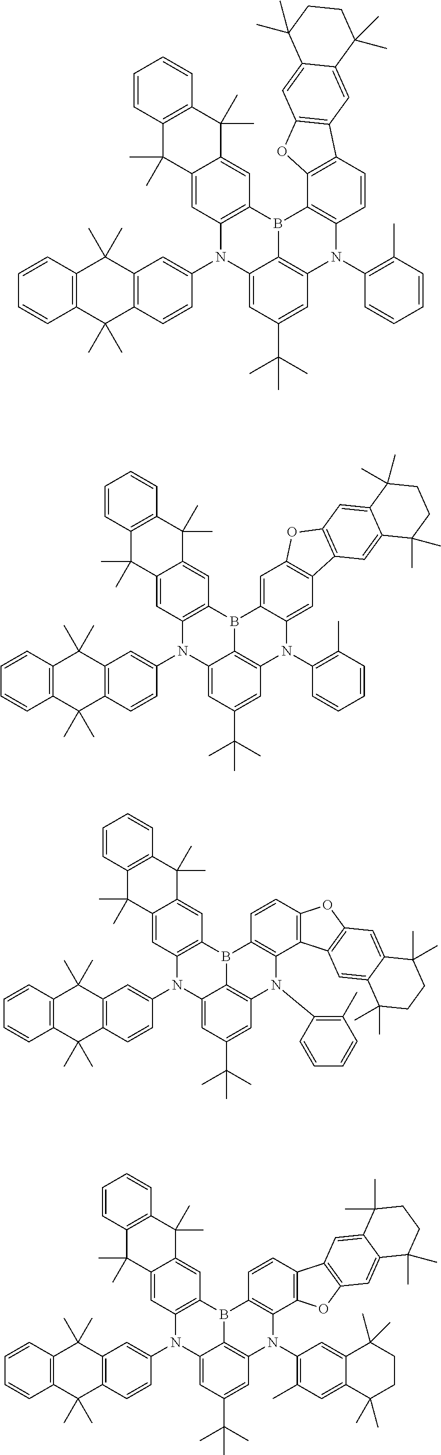

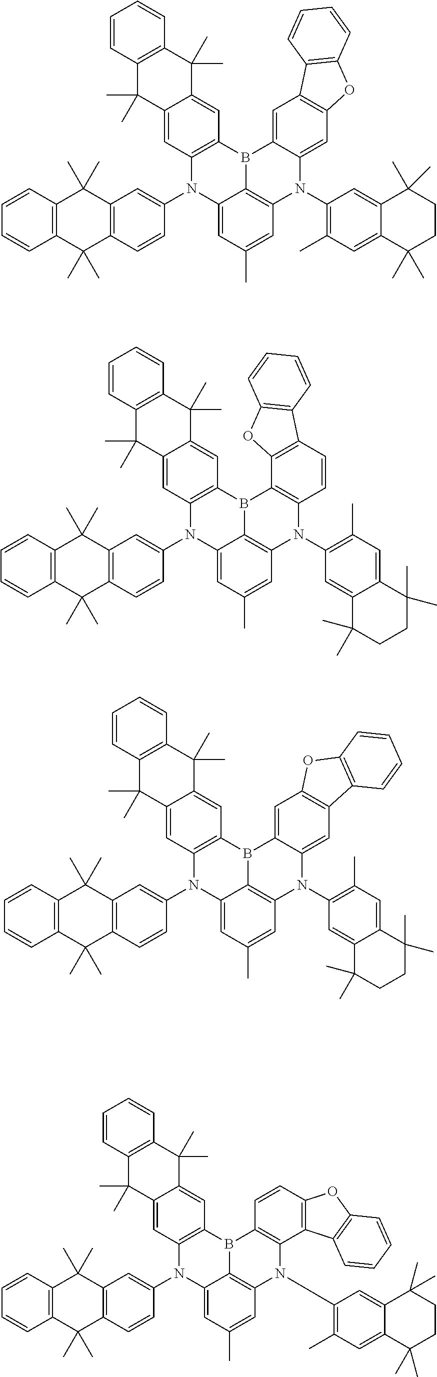

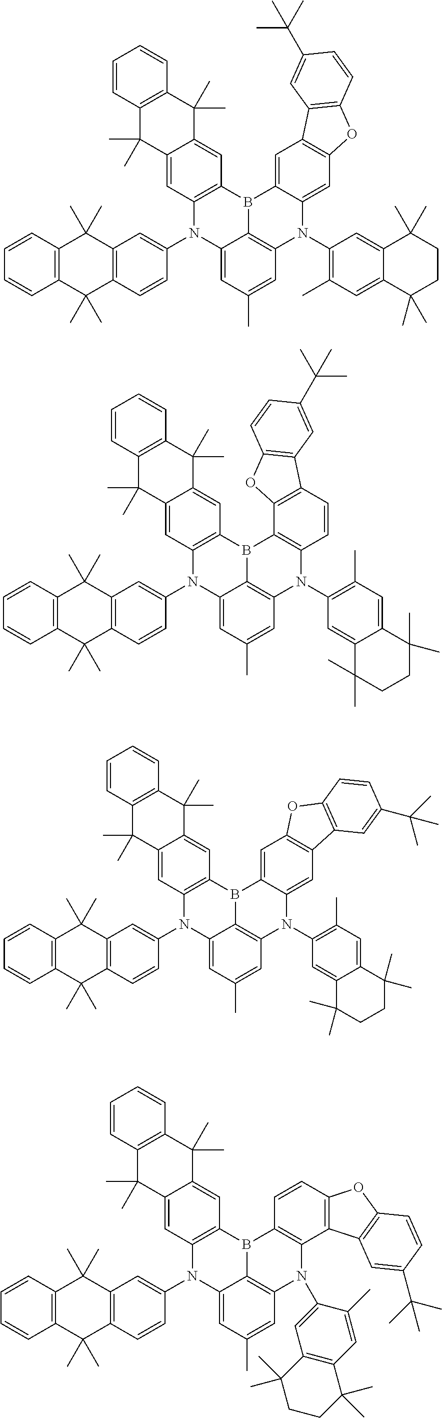

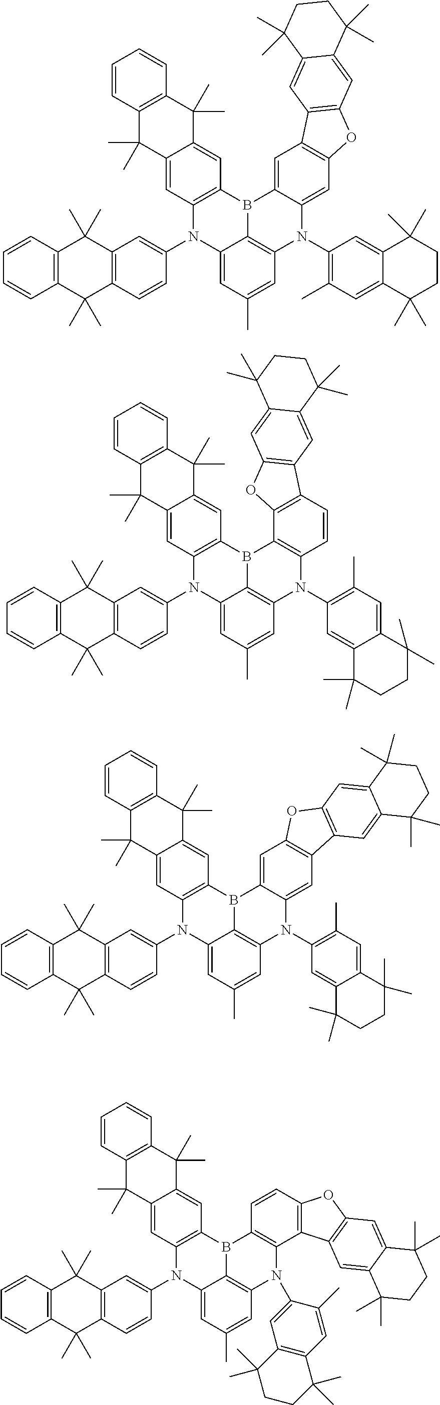

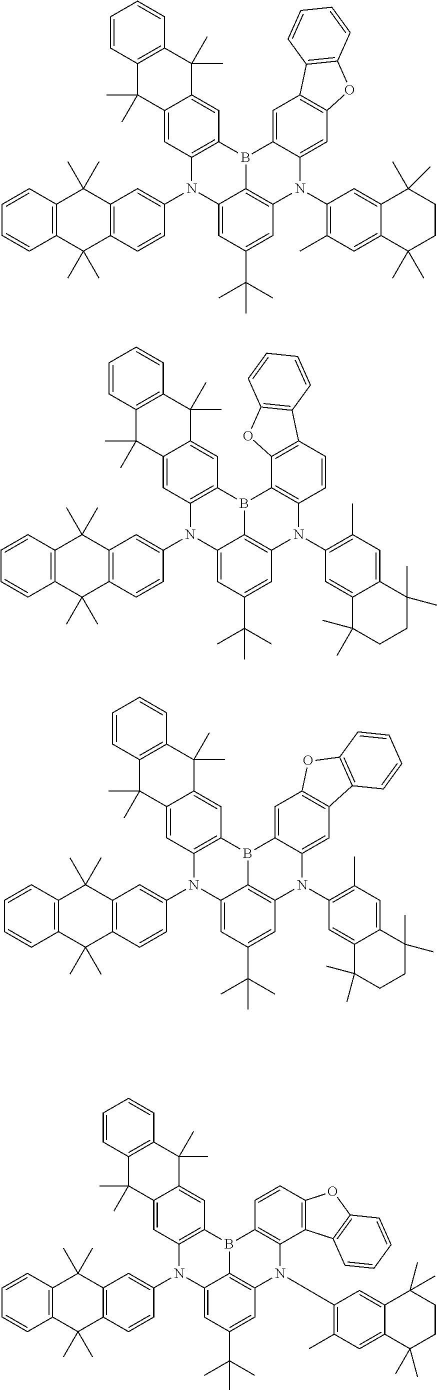

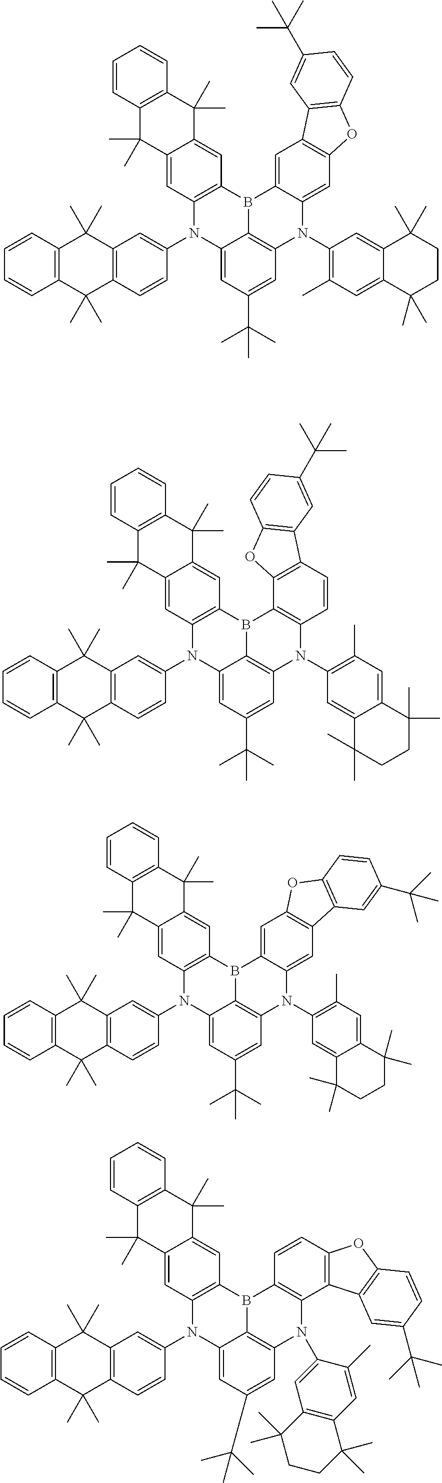

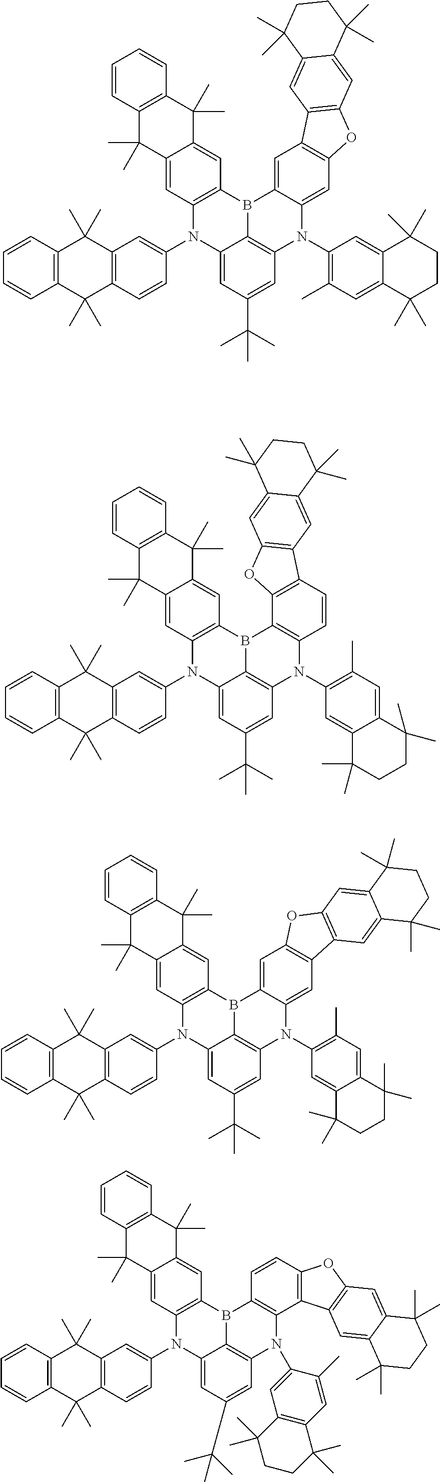

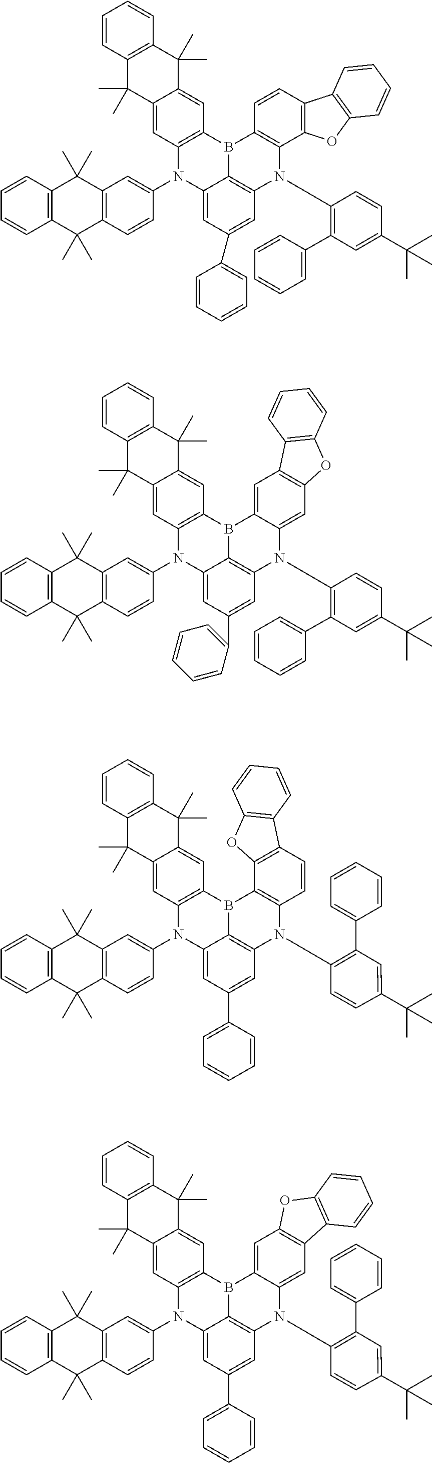

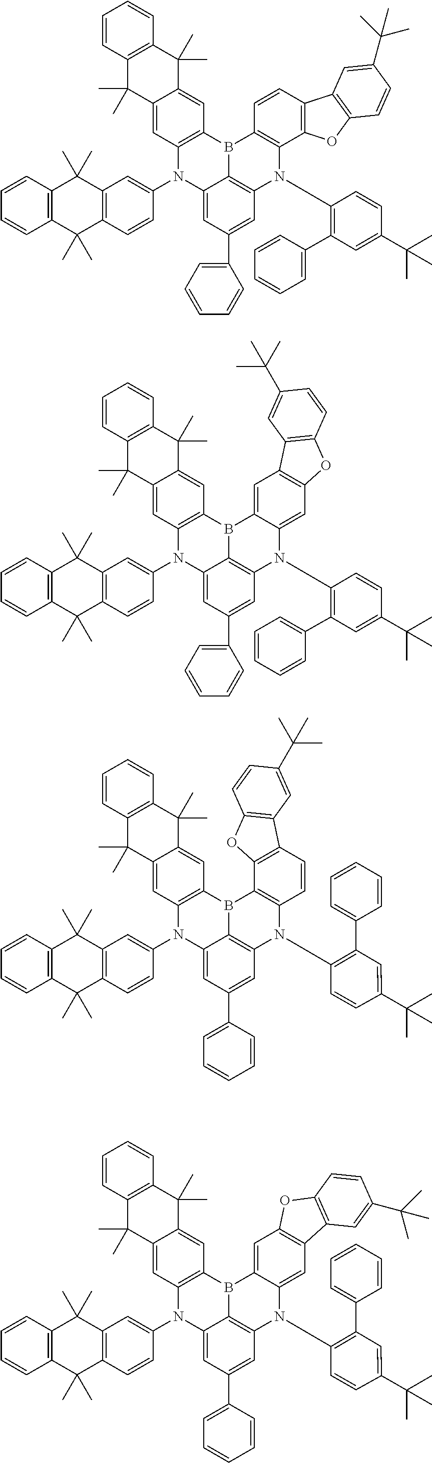

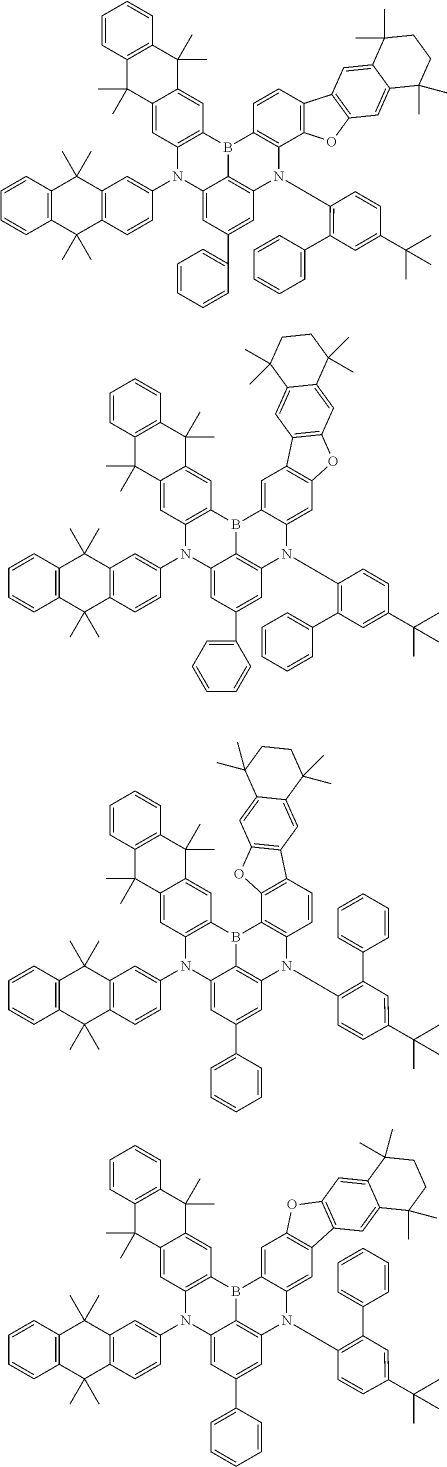

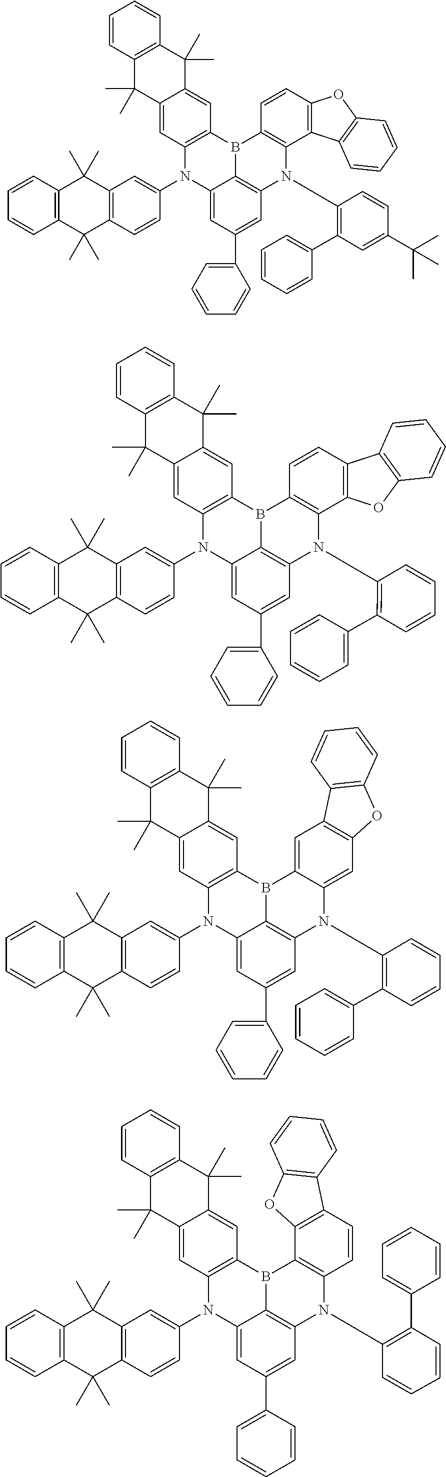

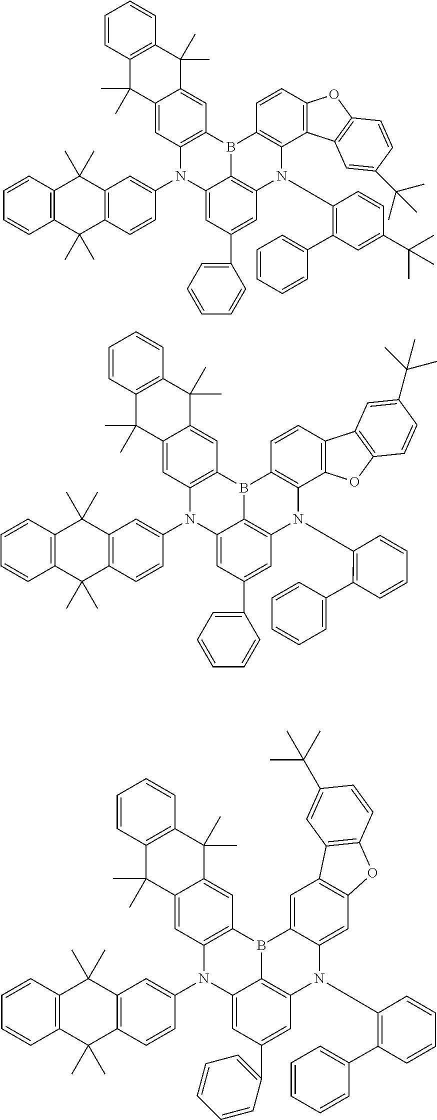 [SMILES: CC(C)(C)c1ccc(N2c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4oc5ccc(C(C)(C)C)cc5c4c32)c(-c2ccccc2)c1 ; CC(C)(C)c1ccc2oc3c4c(ccc3c2c1)B1c2cc3c(cc2N(c2ccc5c(c2)C(C)(C)c2ccccc2C5(C)C)c2cc(-c5ccccc5)cc(c21)N4c1ccccc1-c1ccccc1)C(C)(C)c1ccccc1C3(C)C ; CC(C)(C)c1ccc2oc3cc4c(cc3c2c1)B1c2cc3c(cc2N(c2ccc5c(c2)C(C)(C)c2ccccc2C5(C)C)c2cc(-c5ccccc5)cc(c21)N4c1ccccc1-c1ccccc1)C(C)(C)c1ccccc1C3(C)C]

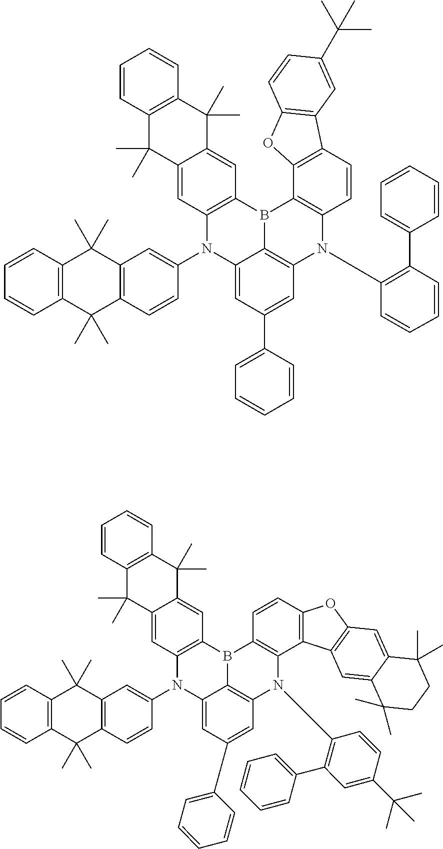 [SMILES: CC(C)(C)c1ccc2oc3c4c(ccc3c2c1)N(c1ccccc1-c1ccccc1)c1cc(-c2ccccc2)cc2c1B4c1cc3c(cc1N2c1ccc2c(c1)C(C)(C)c1ccccc1C2(C)C)C(C)(C)c1ccccc1C3(C)C ; CC(C)(C)c1ccc(N2c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4oc5cc6c(cc5c4c32)C(C)(C)CCC6(C)C)c(-c2ccccc2)c1]

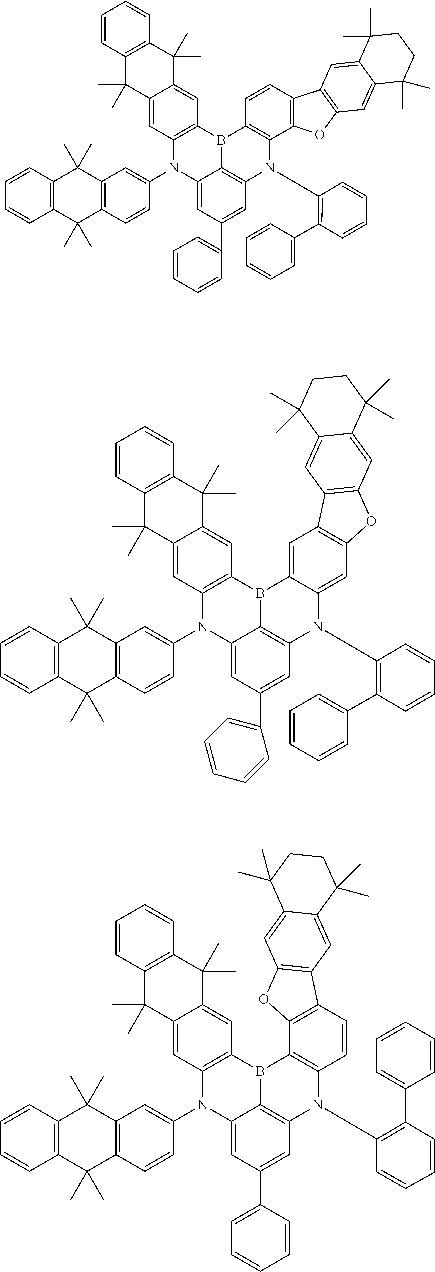 [SMILES: CC1(C)CCC(C)(C)c2cc3c(cc21)oc1c2c(ccc13)B1c3cc4c(cc3N(c3ccc5c(c3)C(C)(C)c3ccccc3C5(C)C)c3cc(-c5ccccc5)cc(c31)N2c1ccccc1-c1ccccc1)C(C)(C)c1ccccc1C4(C)C ; CC1(C)CCC(C)(C)c2cc3c(cc21)oc1cc2c(cc13)B1c3cc4c(cc3N(c3ccc5c(c3)C(C)(C)c3ccccc3C5(C)C)c3cc(-c5ccccc5)cc(c31)N2c1ccccc1-c1ccccc1)C(C)(C)c1ccccc1C4(C)C ; CC1(C)CCC(C)(C)c2cc3c(cc21)oc1c2c(ccc13)N(c1ccccc1-c1ccccc1)c1cc(-c3ccccc3)cc3c1B2c1cc2c(cc1N3c1ccc3c(c1)C(C)(C)c1ccccc1C3(C)C)C(C)(C)c1ccccc1C2(C)C]

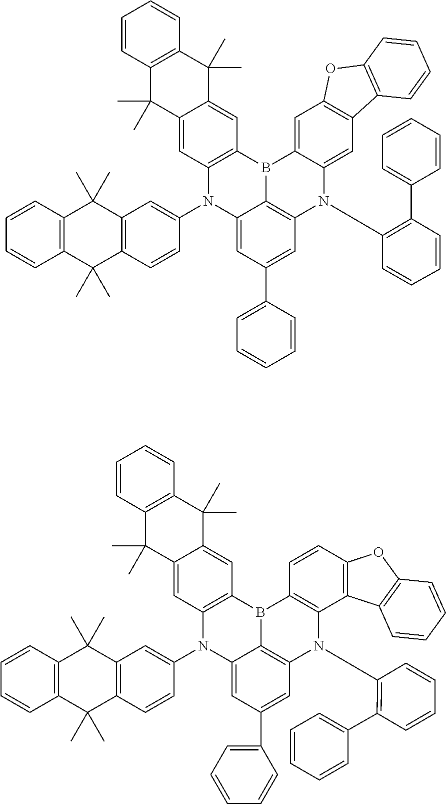 [SMILES: CC1(C)c2ccccc2C(C)(C)c2cc(N3c4cc5c(cc4B4c6cc7oc8ccccc8c7cc6N(c6ccccc6-c6ccccc6)c6cc(-c7ccccc7)cc3c64)C(C)(C)c3ccccc3C5(C)C)ccc21 ; CC1(C)c2ccccc2C(C)(C)c2cc(N3c4cc5c(cc4B4c6ccc7oc8ccccc8c7c6N(c6ccccc6-c6ccccc6)c6cc(-c7ccccc7)cc3c64)C(C)(C)c3ccccc3C5(C)C)ccc21]

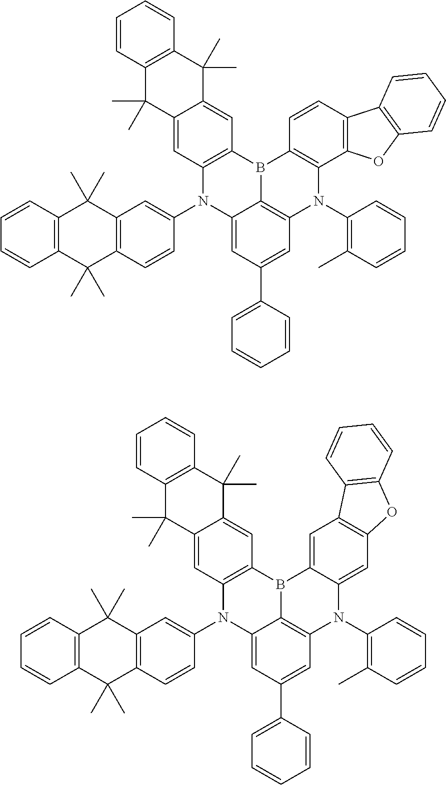 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(oc4ccccc43)c21 ; Cc1ccccc1N1c2cc3oc4ccccc4c3cc2B2c3cc4c(cc3N(c3ccc5c(c3)C(C)(C)c3ccccc3C5(C)C)c3cc(-c5ccccc5)cc1c32)C(C)(C)c1ccccc1C4(C)C]

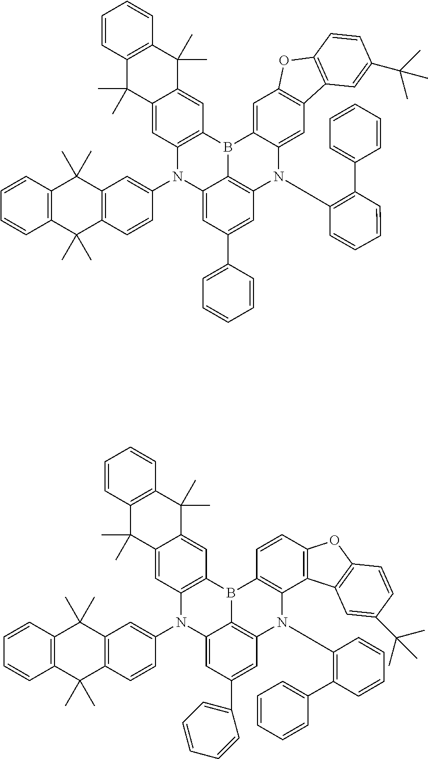 [SMILES: CC(C)(C)c1ccc2oc3cc4c(cc3c2c1)N(c1ccccc1-c1ccccc1)c1cc(-c2ccccc2)cc2c1B4c1cc3c(cc1N2c1ccc2c(c1)C(C)(C)c1ccccc1C2(C)C)C(C)(C)c1ccccc1C3(C)C ; CC(C)(C)c1ccc2oc3ccc4c(c3c2c1)N(c1ccccc1-c1ccccc1)c1cc(-c2ccccc2)cc2c1B4c1cc3c(cc1N2c1ccc2c(c1)C(C)(C)c1ccccc1C2(C)C)C(C)(C)c1ccccc1C3(C)C]

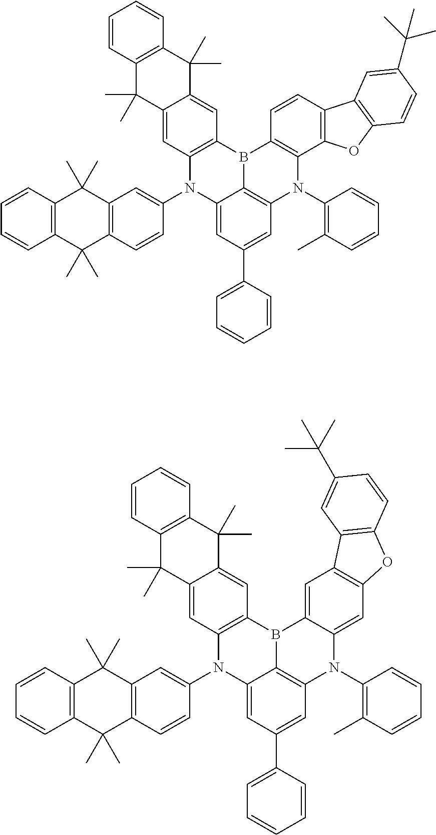 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)c3ccccc3C5(C)C)c3cc(-c5ccccc5)cc1c32)C(C)(C)c1ccccc1C4(C)C]

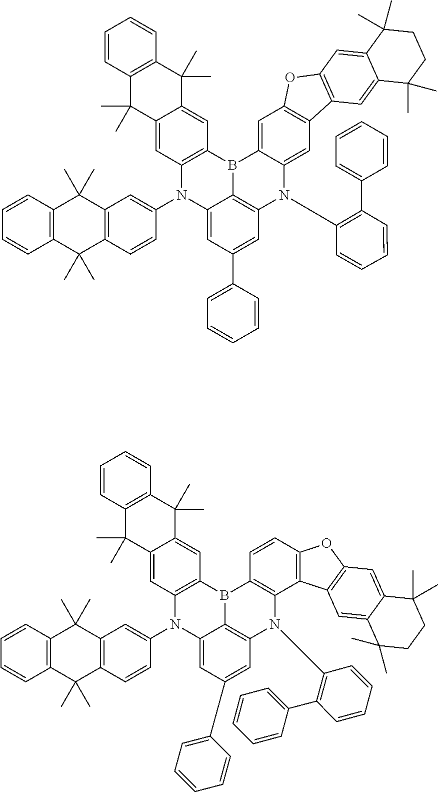 [SMILES: CC1(C)CCC(C)(C)c2cc3c(cc21)oc1cc2c(cc13)N(c1ccccc1-c1ccccc1)c1cc(-c3ccccc3)cc3c1B2c1cc2c(cc1N3c1ccc3c(c1)C(C)(C)c1ccccc1C3(C)C)C(C)(C)c1ccccc1C2(C)C ; CC1(C)CCC(C)(C)c2cc3c(cc21)oc1ccc2c(c13)N(c1ccccc1-c1ccccc1)c1cc(-c3ccccc3)cc3c1B2c1cc2c(cc1N3c1ccc3c(c1)C(C)(C)c1ccccc1C3(C)C)C(C)(C)c1ccccc1C2(C)C]

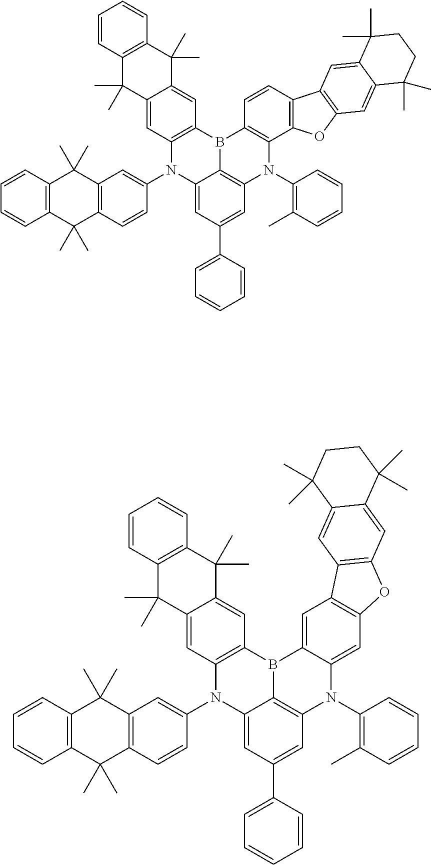 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(oc4cc5c(cc43)C(C)(C)CCC5(C)C)c21 ; Cc1ccccc1N1c2cc3oc4cc5c(cc4c3cc2B2c3cc4c(cc3N(c3ccc6c(c3)C(C)(C)c3ccccc3C6(C)C)c3cc(-c6ccccc6)cc1c32)C(C)(C)c1ccccc1C4(C)C)C(C)(C)CCC5(C)C]

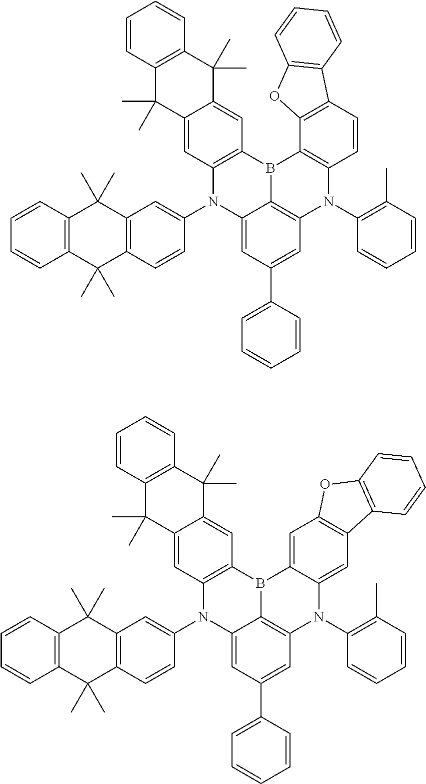 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2oc2ccccc21 ; Cc1ccccc1N1c2cc3c(cc2B2c4cc5c(cc4N(c4ccc6c(c4)C(C)(C)c4ccccc4C6(C)C)c4cc(-c6ccccc6)cc1c42)C(C)(C)c1ccccc1C5(C)C)oc1ccccc13]

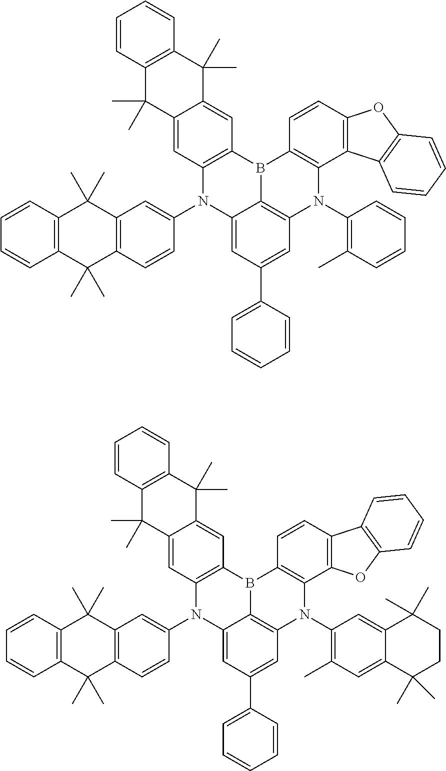 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3oc4ccccc4c3c21 ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(oc5ccccc54)c31)C(C)(C)CCC2(C)C]

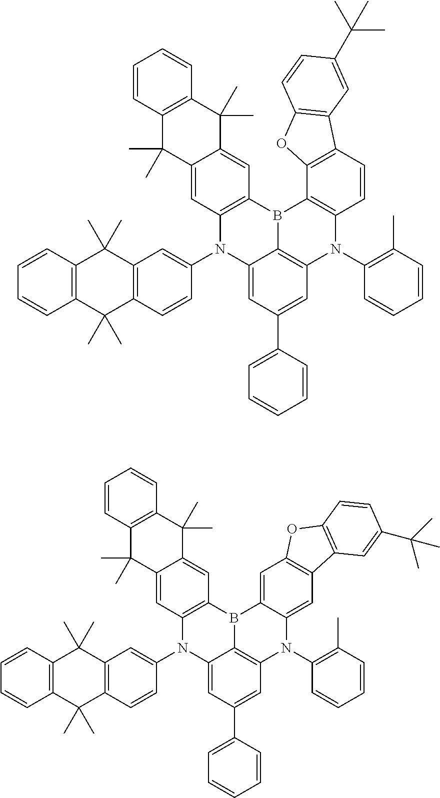 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2oc2ccc(C(C)(C)C)cc21 ; Cc1ccccc1N1c2cc3c(cc2B2c4cc5c(cc4N(c4ccc6c(c4)C(C)(C)c4ccccc4C6(C)C)c4cc(-c6ccccc6)cc1c42)C(C)(C)c1ccccc1C5(C)C)oc1ccc(C(C)(C)C)cc13]

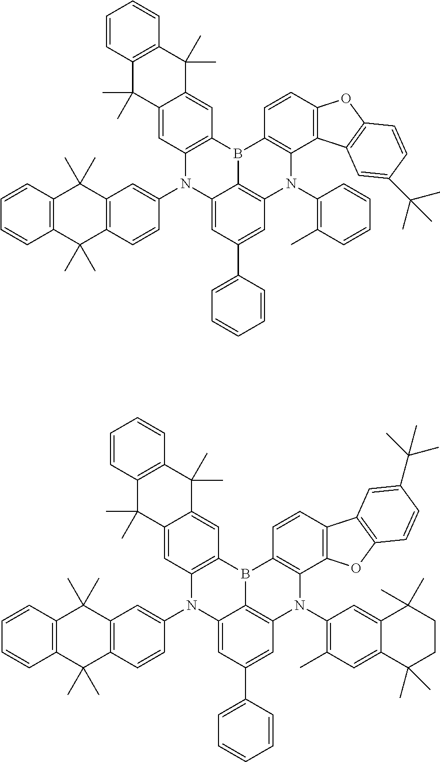 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3oc4ccc(C(C)(C)C)cc4c3c21 ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(oc5ccc(C(C)(C)C)cc54)c31)C(C)(C)CCC2(C)C]

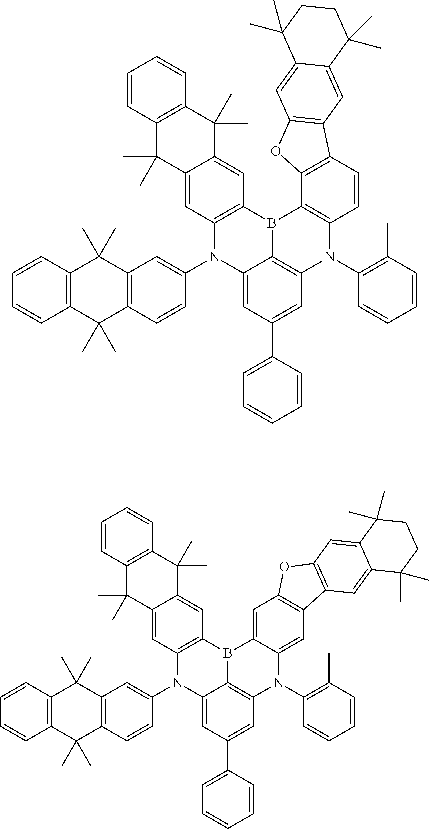 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2oc2cc3c(cc21)C(C)(C)CCC3(C)C ; Cc1ccccc1N1c2cc3c(cc2B2c4cc5c(cc4N(c4ccc6c(c4)C(C)(C)c4ccccc4C6(C)C)c4cc(-c6ccccc6)cc1c42)C(C)(C)c1ccccc1C5(C)C)oc1cc2c(cc13)C(C)(C)CCC2(C)C]

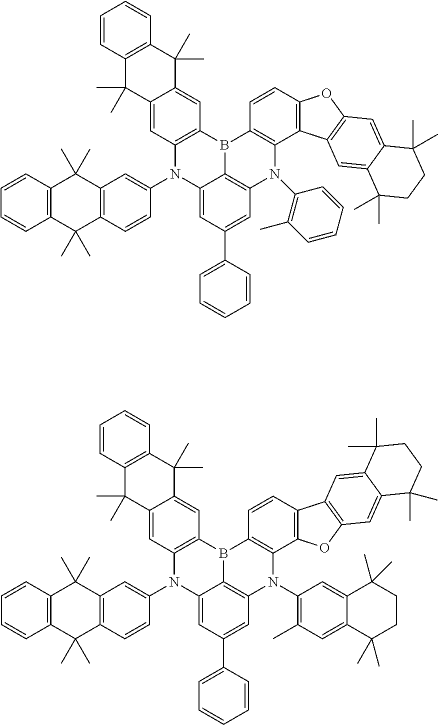 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3oc4cc5c(cc4c3c21)C(C)(C)CCC5(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(oc5cc6c(cc54)C(C)(C)CCC6(C)C)c31)C(C)(C)CCC2(C)C]

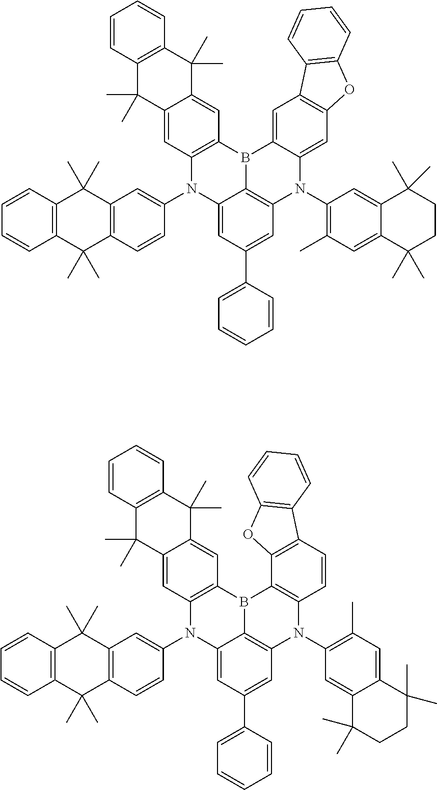 [SMILES: Cc1cc2c(cc1N1c3cc4oc5ccccc5c4cc3B3c4cc5c(cc4N(c4ccc6c(c4)C(C)(C)c4ccccc4C6(C)C)c4cc(-c6ccccc6)cc1c43)C(C)(C)c1ccccc1C5(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3oc3ccccc31)C(C)(C)CCC2(C)C]

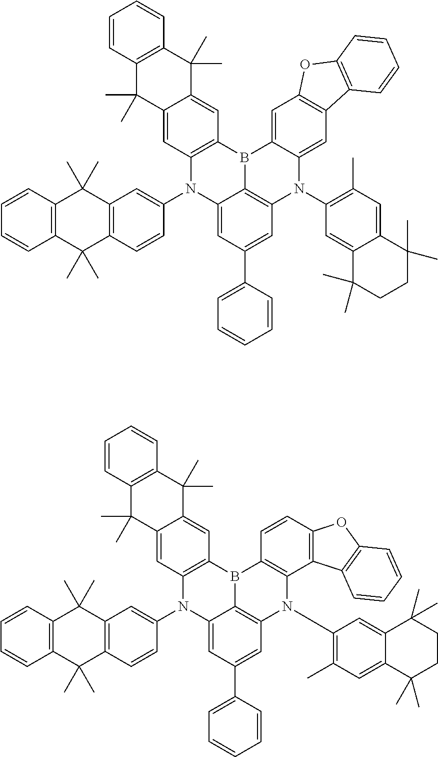 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)oc1ccccc14)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4oc5ccccc5c4c31)C(C)(C)CCC2(C)C]

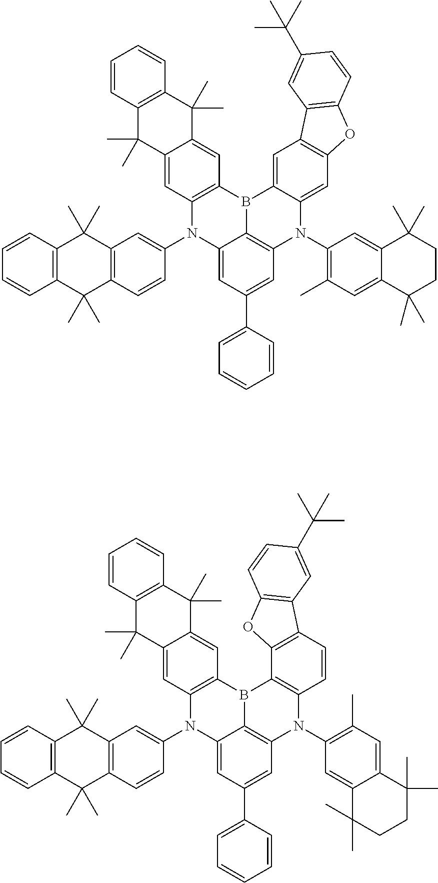 [SMILES: Cc1cc2c(cc1N1c3cc4oc5ccc(C(C)(C)C)cc5c4cc3B3c4cc5c(cc4N(c4ccc6c(c4)C(C)(C)c4ccccc4C6(C)C)c4cc(-c6ccccc6)cc1c43)C(C)(C)c1ccccc1C5(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3oc3ccc(C(C)(C)C)cc31)C(C)(C)CCC2(C)C]

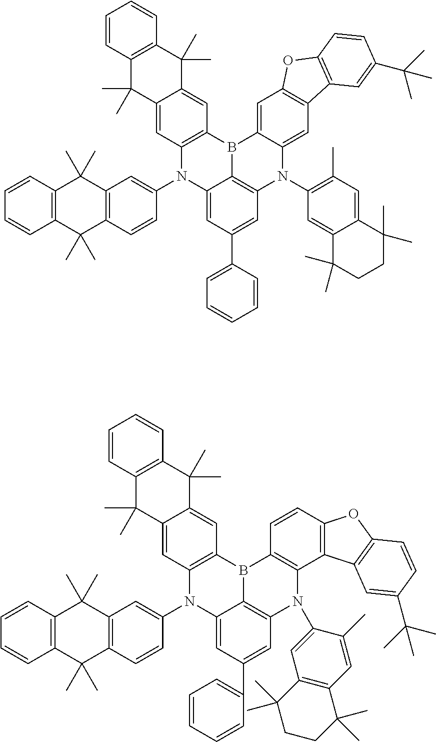 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)oc1ccc(C(C)(C)C)cc14)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4oc5ccc(C(C)(C)C)cc5c4c31)C(C)(C)CCC2(C)C]

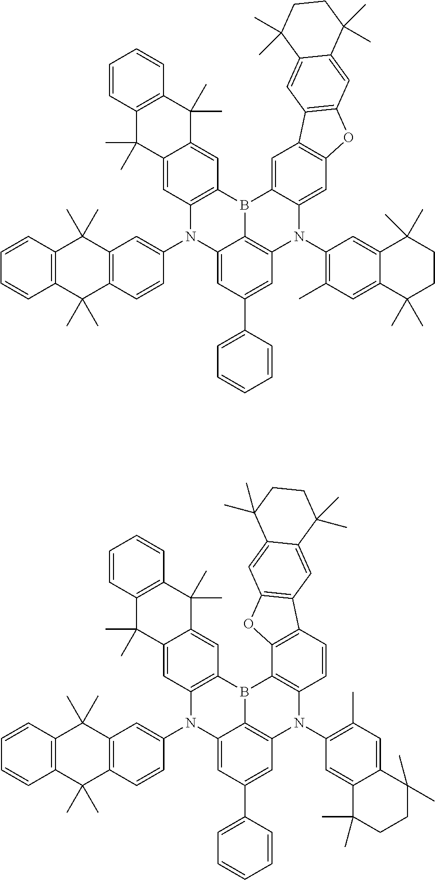 [SMILES: Cc1cc2c(cc1N1c3cc4oc5cc6c(cc5c4cc3B3c4cc5c(cc4N(c4ccc7c(c4)C(C)(C)c4ccccc4C7(C)C)c4cc(-c7ccccc7)cc1c43)C(C)(C)c1ccccc1C5(C)C)C(C)(C)CCC6(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3oc3cc4c(cc31)C(C)(C)CCC4(C)C)C(C)(C)CCC2(C)C]

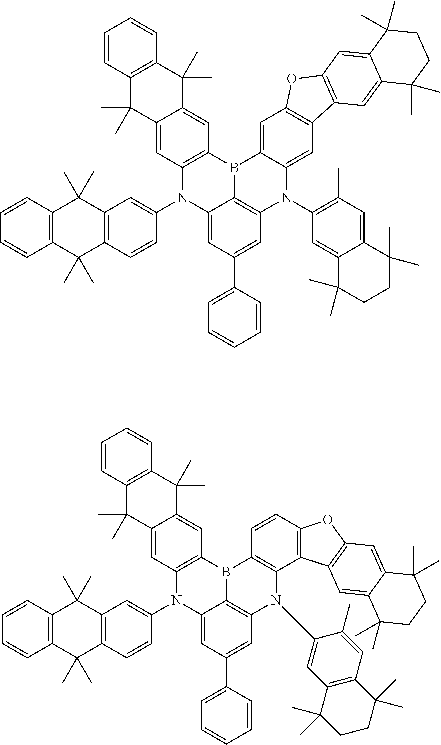 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)oc1cc3c(cc14)C(C)(C)CCC3(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4oc5cc6c(cc5c4c31)C(C)(C)CCC6(C)C)C(C)(C)CCC2(C)C]

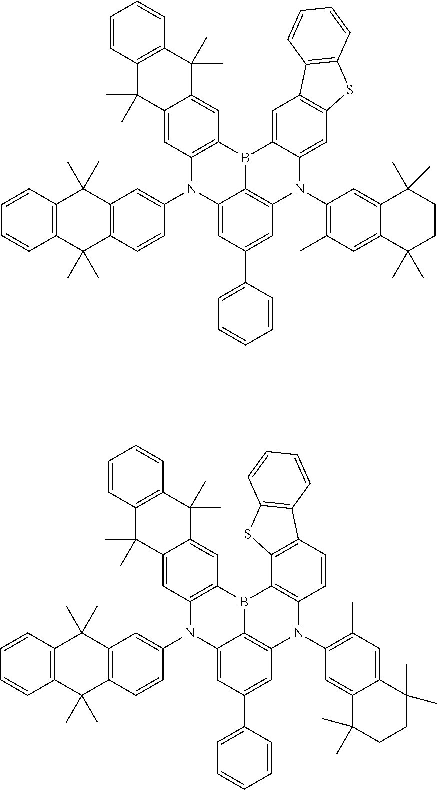 [SMILES: Cc1cc2c(cc1N1c3cc4sc5ccccc5c4cc3B3c4cc5c(cc4N(c4ccc6c(c4)C(C)(C)c4ccccc4C6(C)C)c4cc(-c6ccccc6)cc1c43)C(C)(C)c1ccccc1C5(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3sc3ccccc31)C(C)(C)CCC2(C)C]

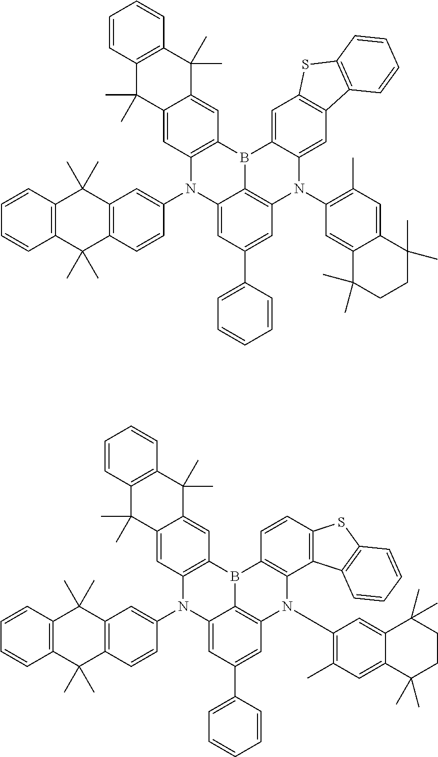 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)sc1ccccc14)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4sc5ccccc5c4c31)C(C)(C)CCC2(C)C]

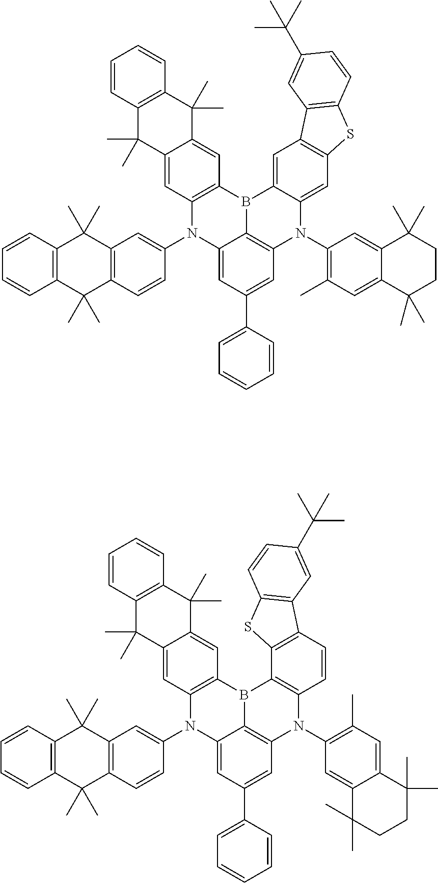 [SMILES: Cc1cc2c(cc1N1c3cc4sc5ccc(C(C)(C)C)cc5c4cc3B3c4cc5c(cc4N(c4ccc6c(c4)C(C)(C)c4ccccc4C6(C)C)c4cc(-c6ccccc6)cc1c43)C(C)(C)c1ccccc1C5(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3sc3ccc(C(C)(C)C)cc31)C(C)(C)CCC2(C)C]

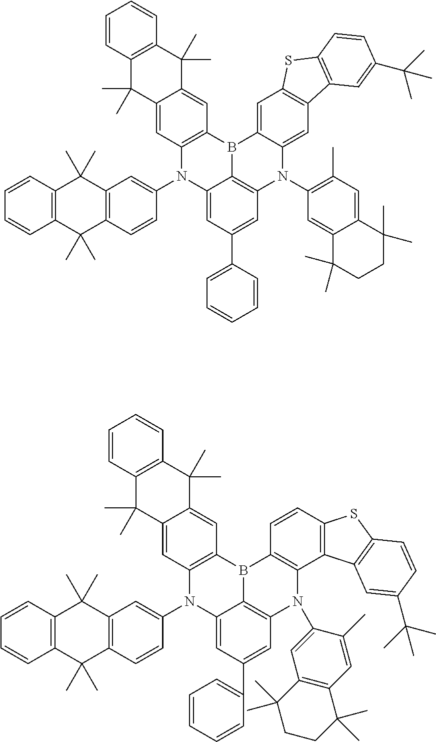 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)sc1ccc(C(C)(C)C)cc14)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4sc5ccc(C(C)(C)C)cc5c4c31)C(C)(C)CCC2(C)C]

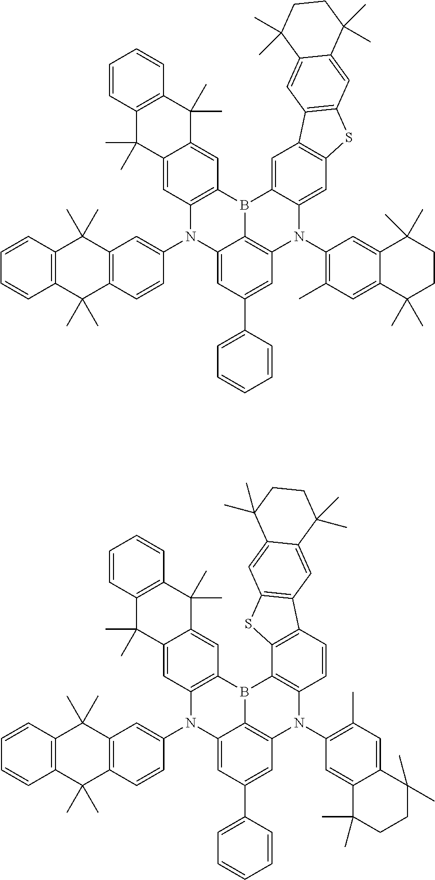 [SMILES: Cc1cc2c(cc1N1c3cc4sc5cc6c(cc5c4cc3B3c4cc5c(cc4N(c4ccc7c(c4)C(C)(C)c4ccccc4C7(C)C)c4cc(-c7ccccc7)cc1c43)C(C)(C)c1ccccc1C5(C)C)C(C)(C)CCC6(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3sc3cc4c(cc31)C(C)(C)CCC4(C)C)C(C)(C)CCC2(C)C]

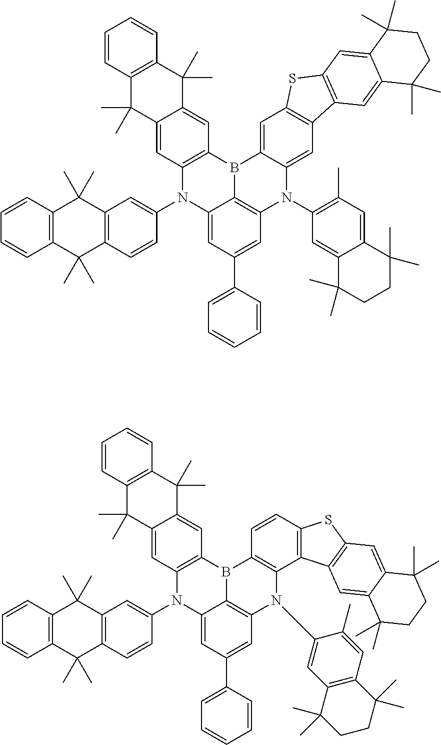 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)sc1cc3c(cc14)C(C)(C)CCC3(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4sc5cc6c(cc5c4c31)C(C)(C)CCC6(C)C)C(C)(C)CCC2(C)C]

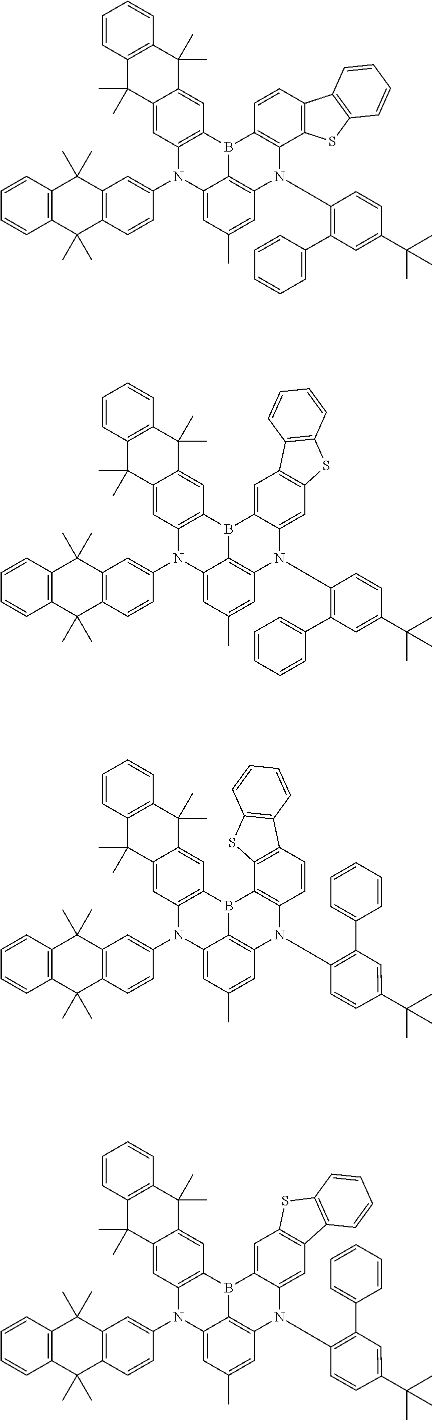

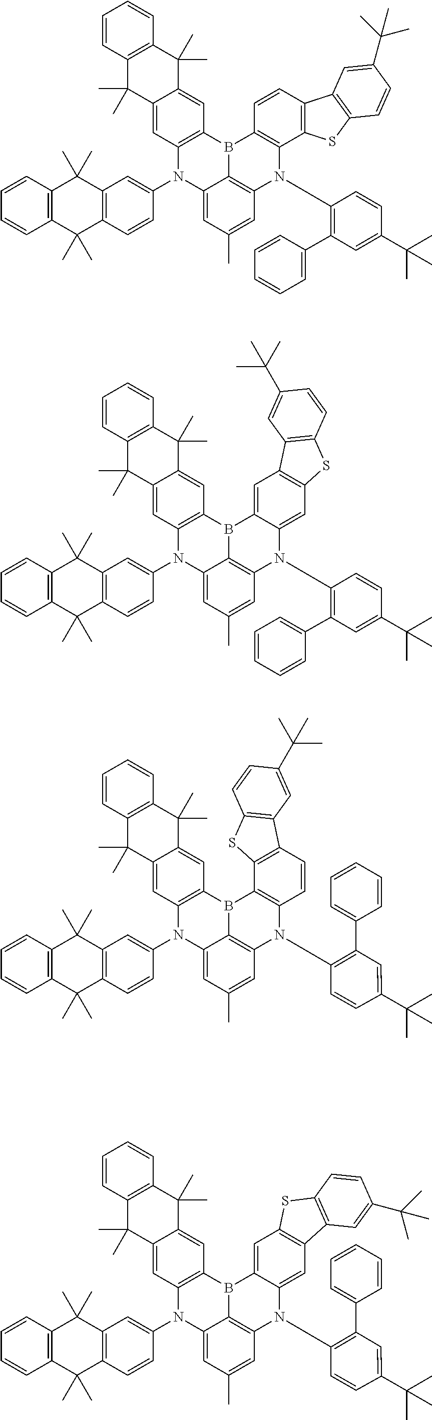

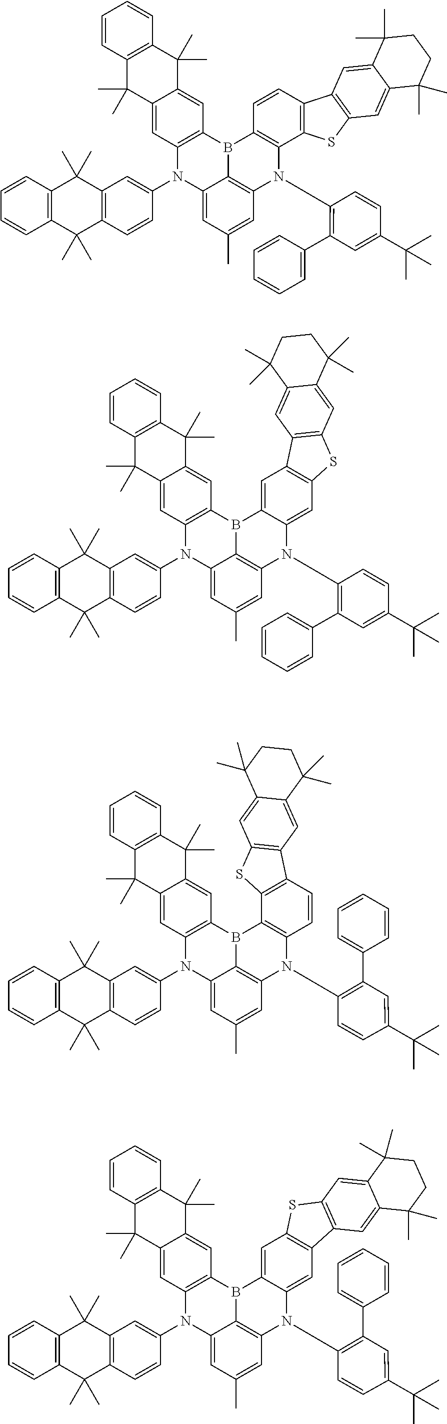

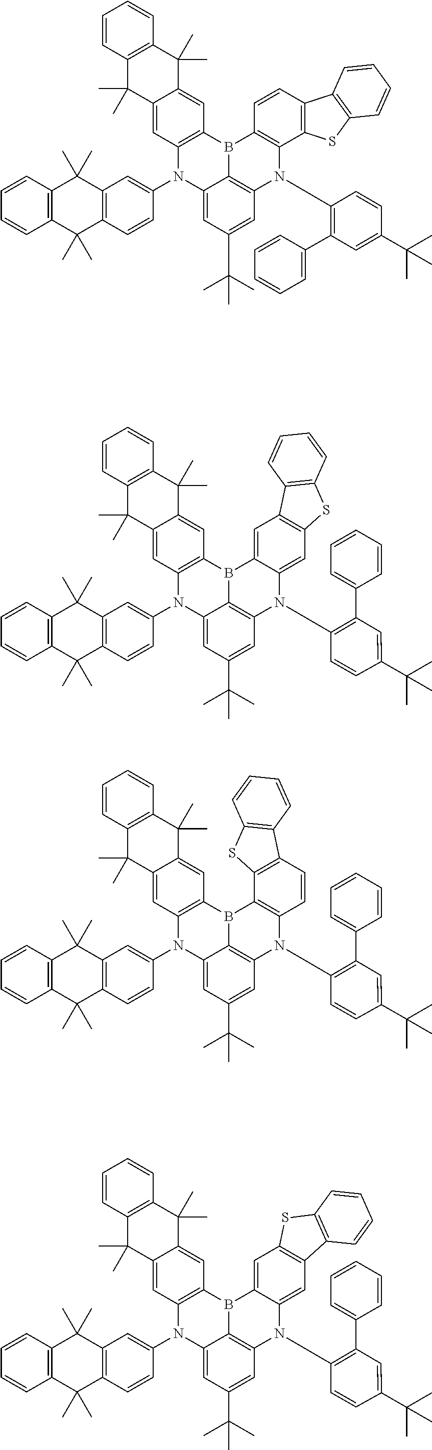

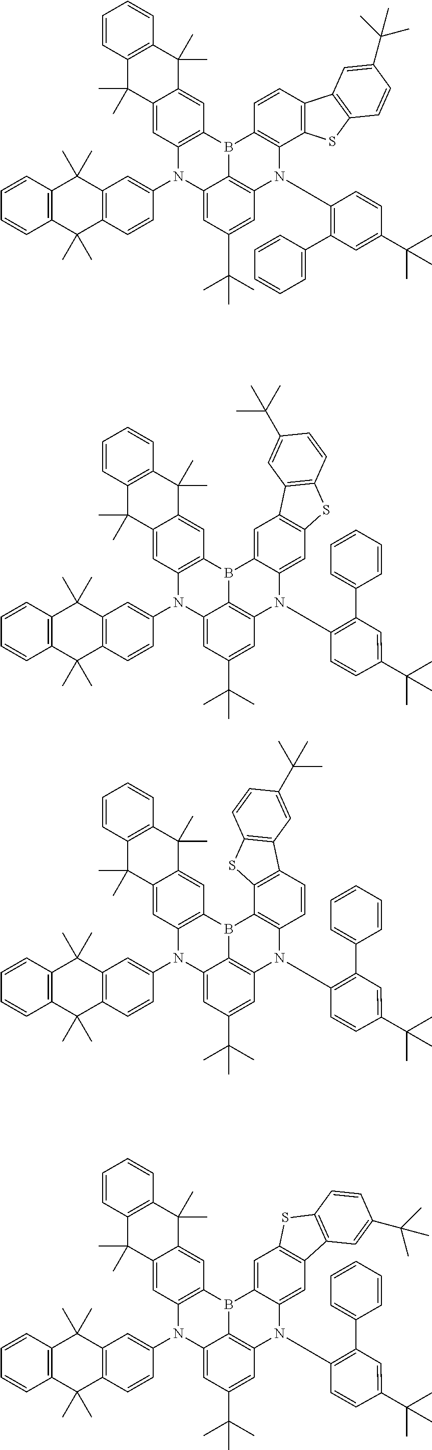

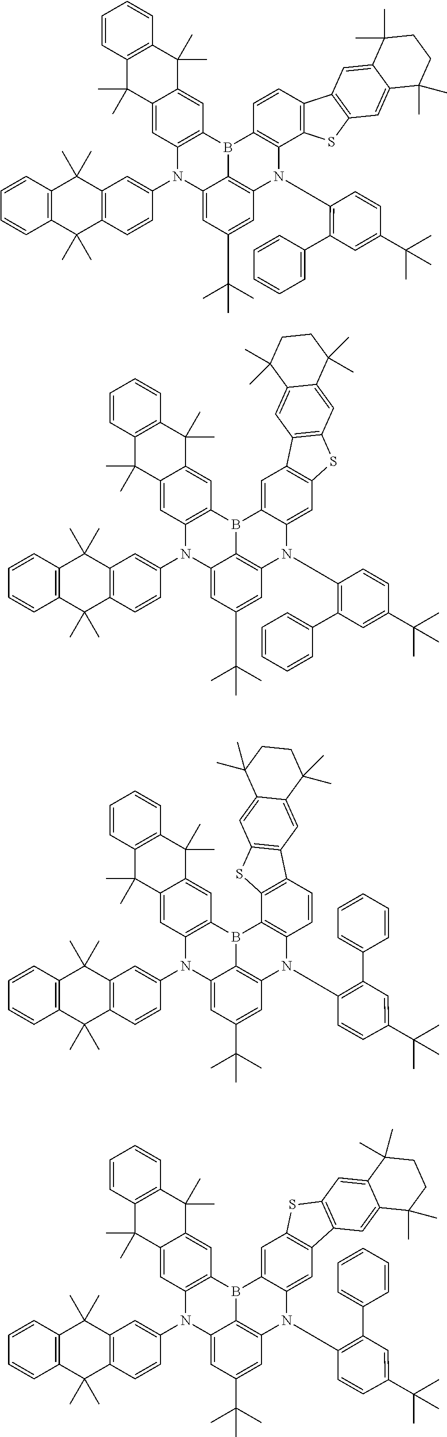

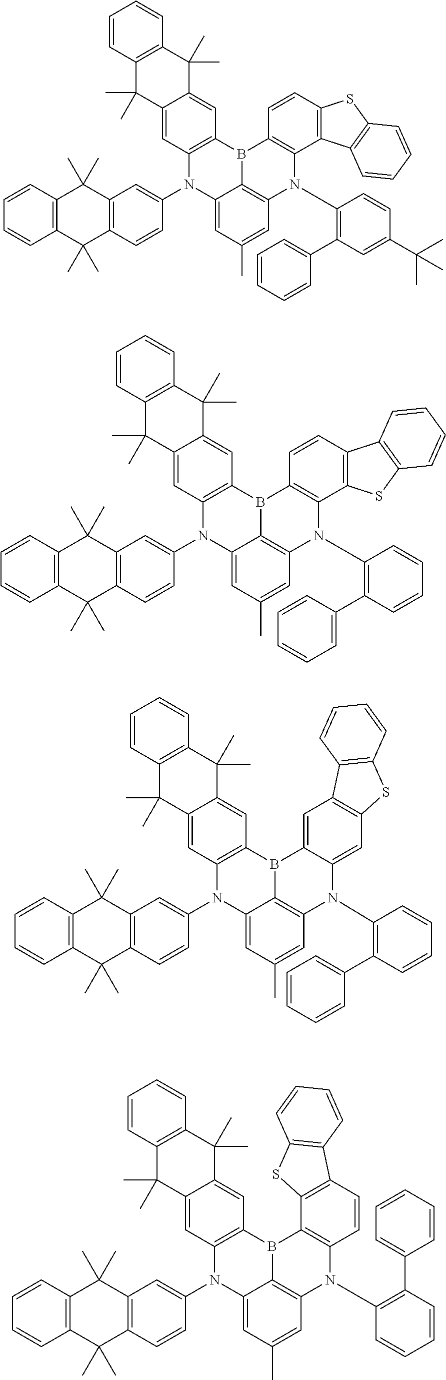

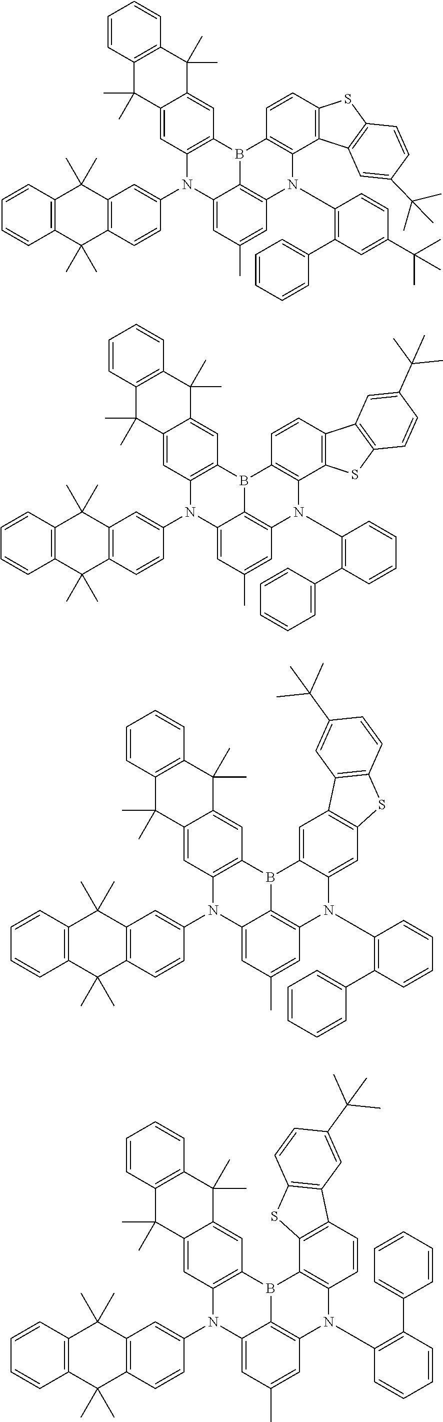

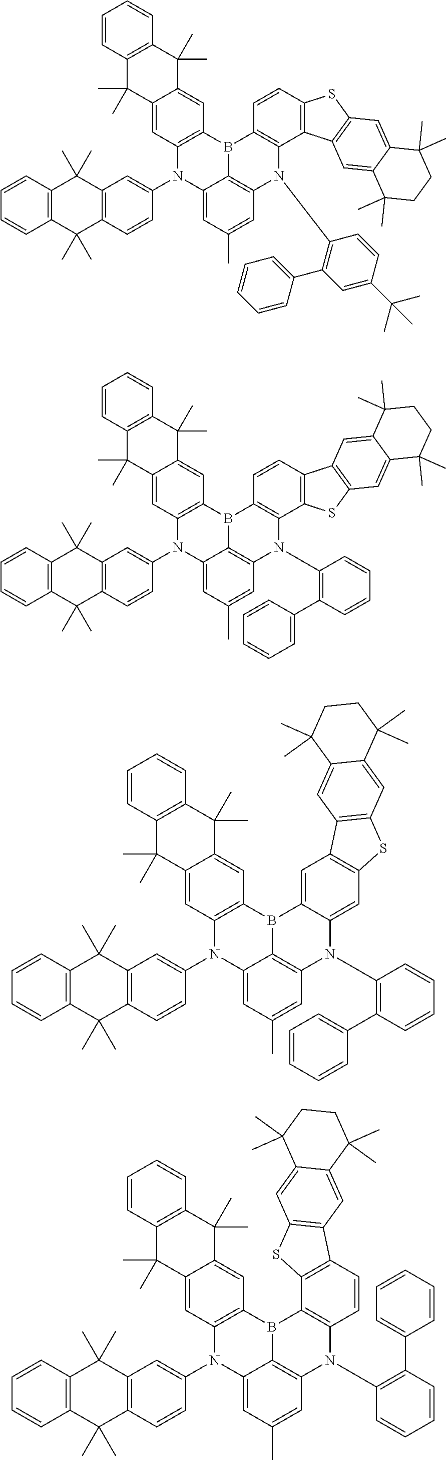

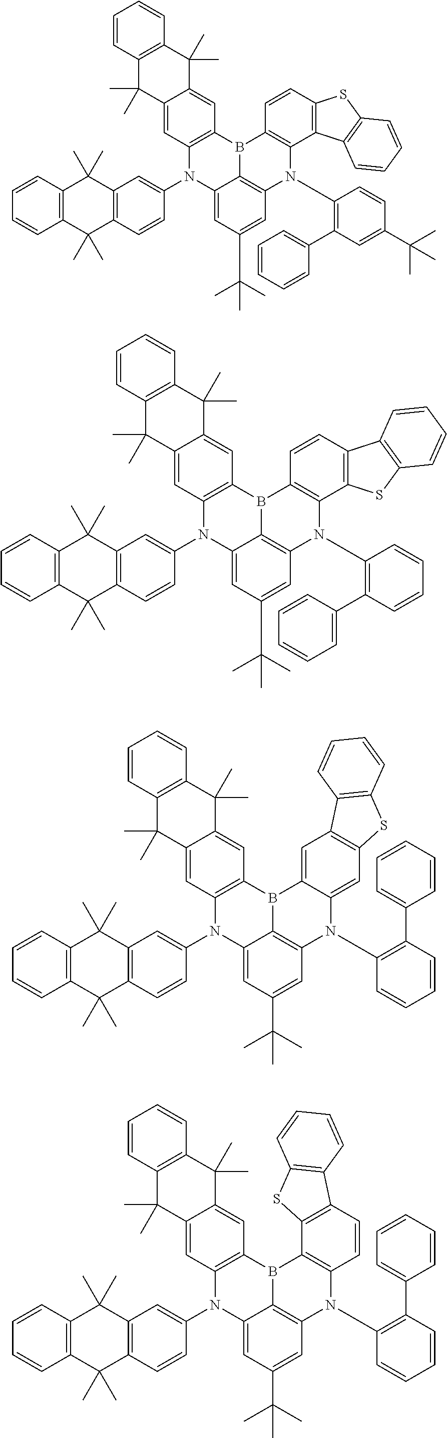

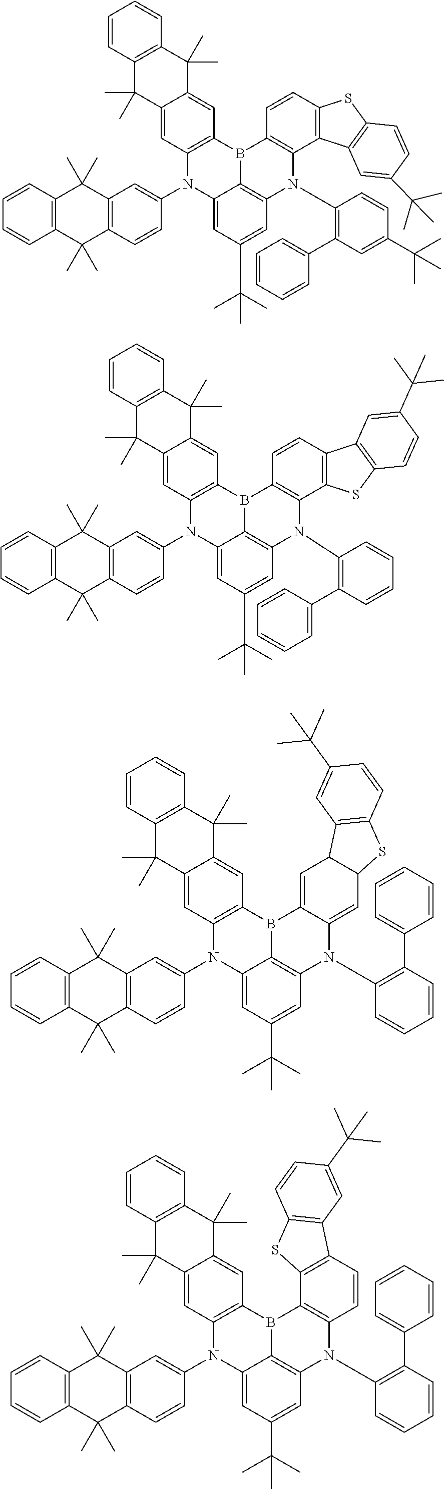

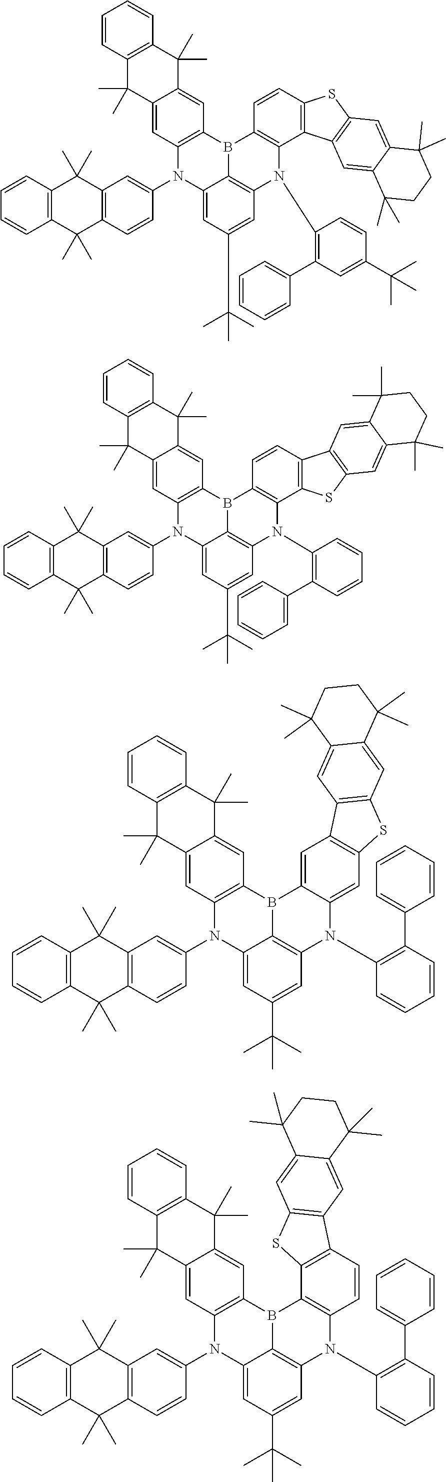

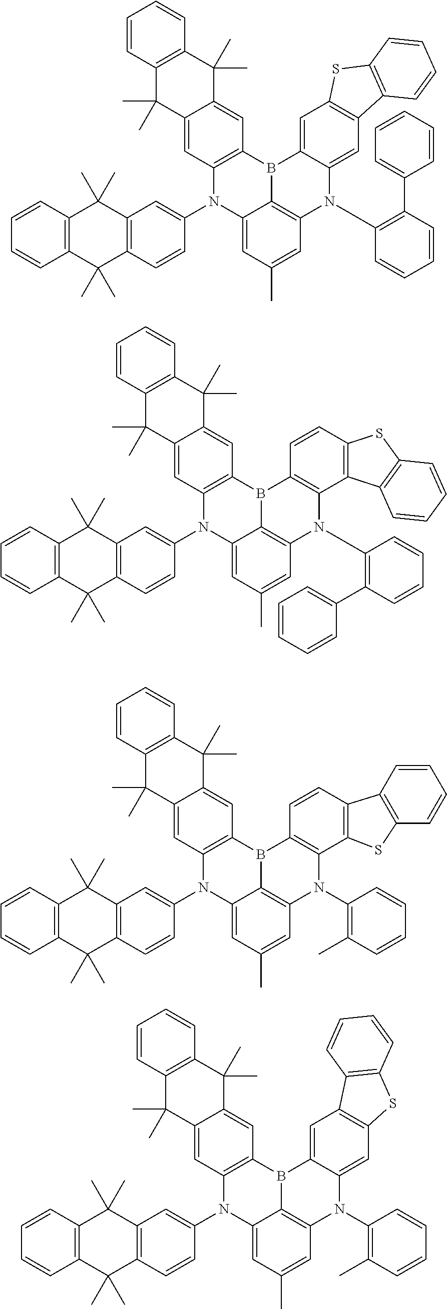

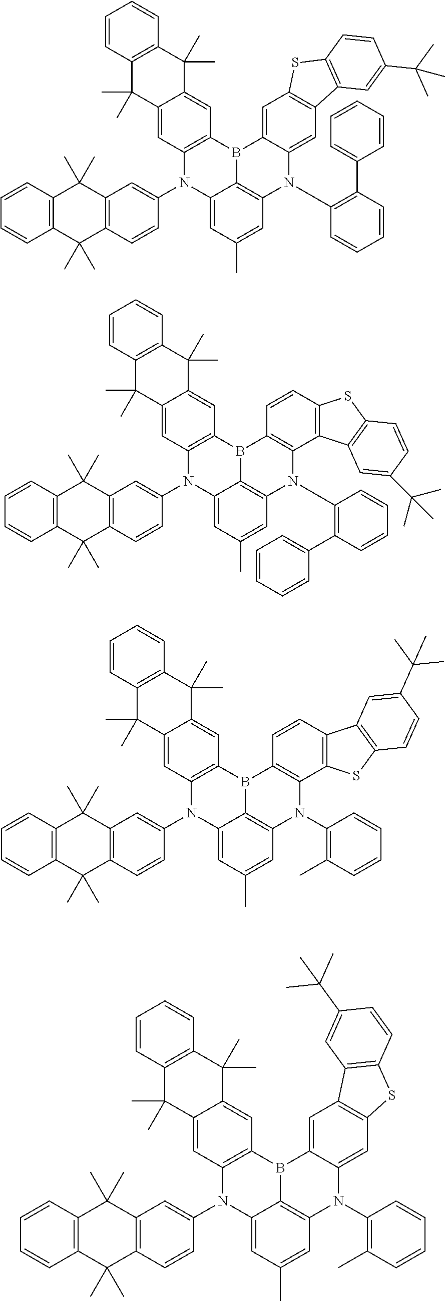

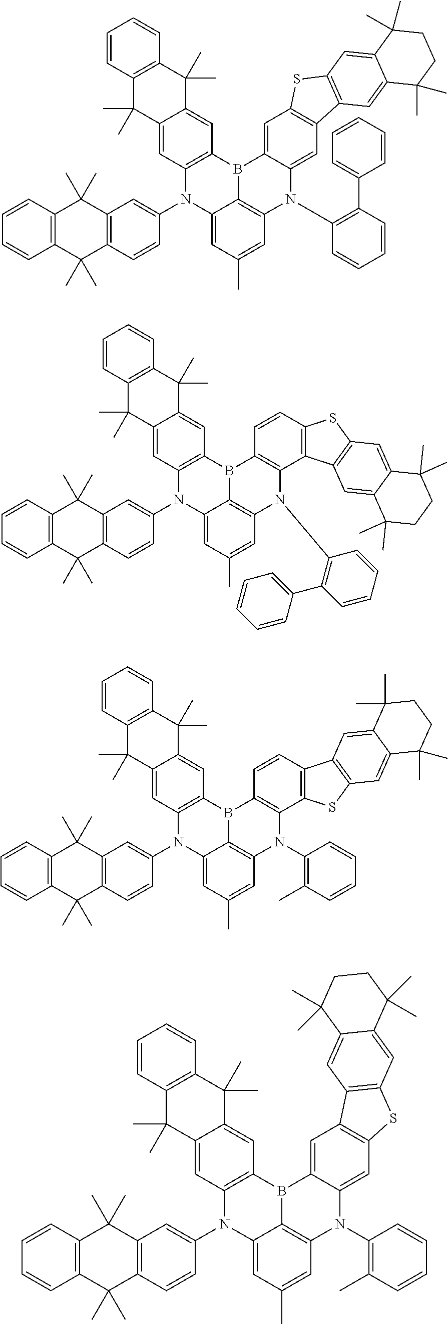

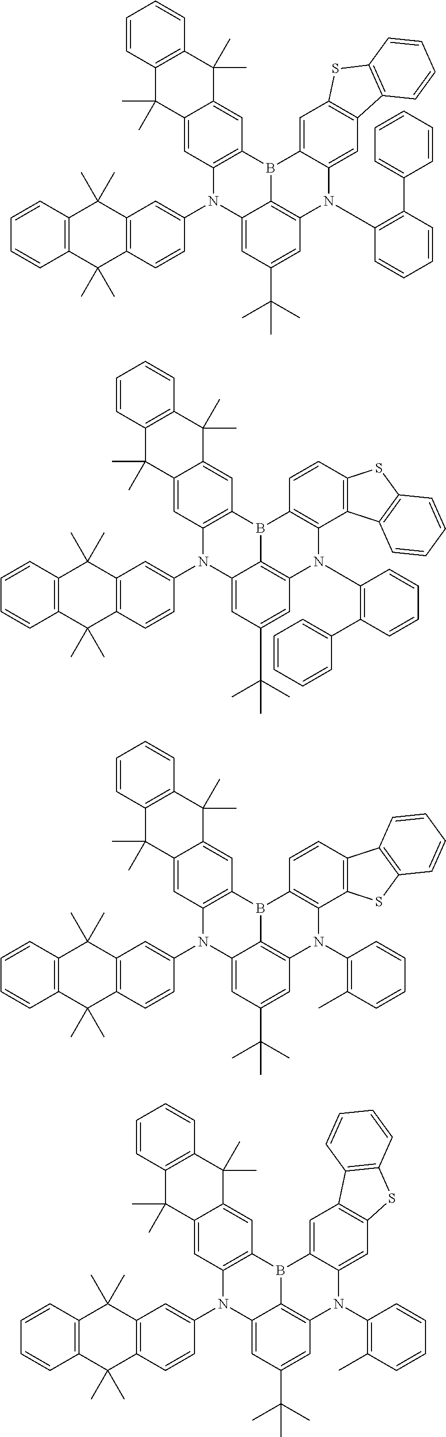

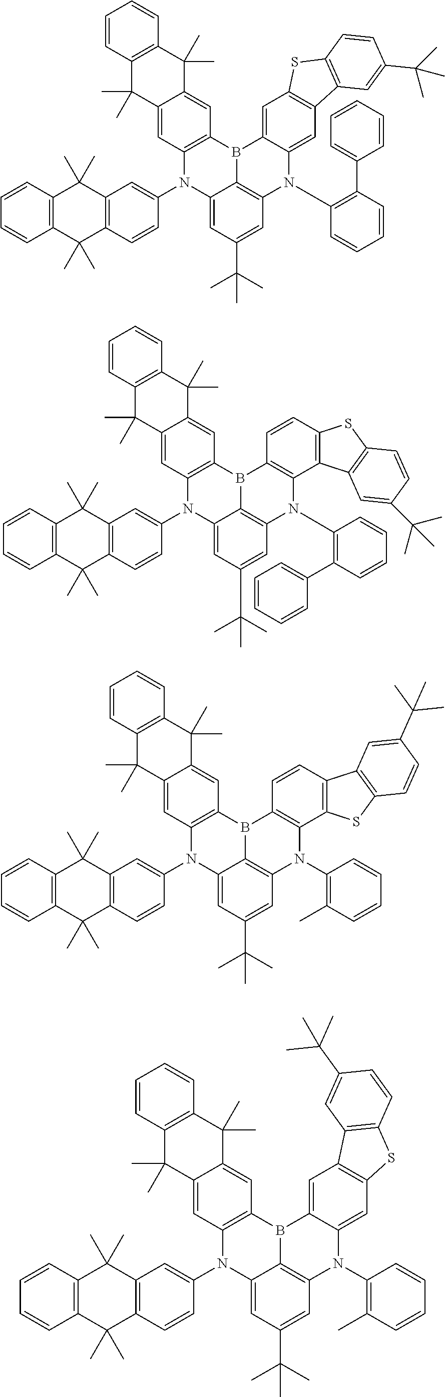

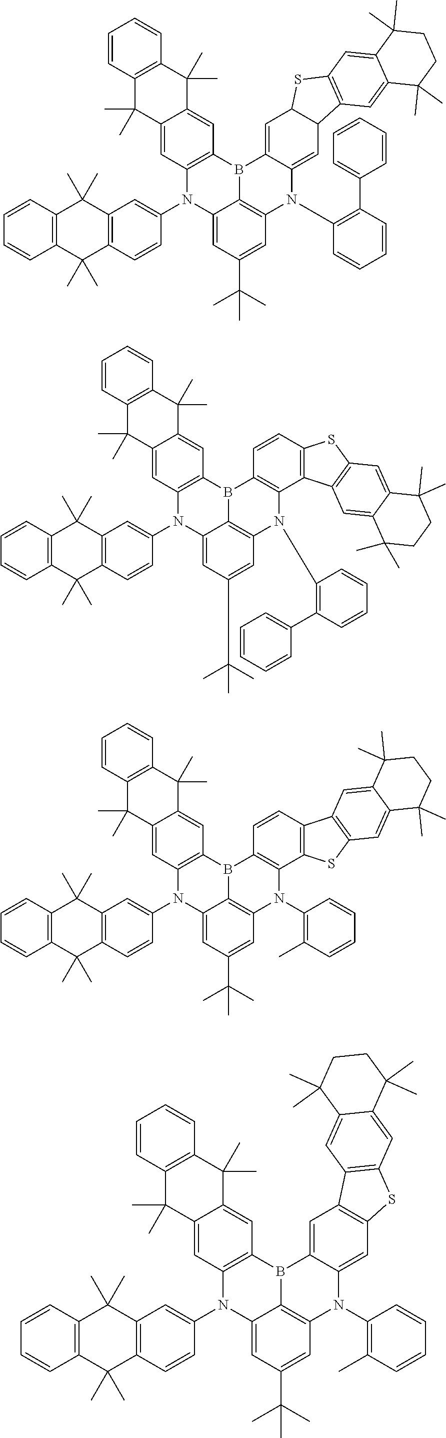

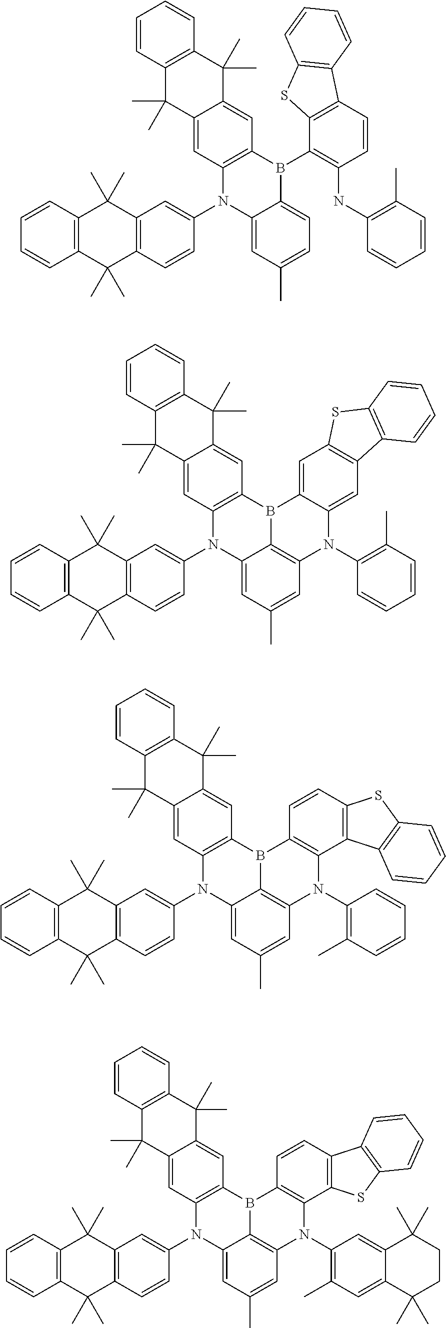

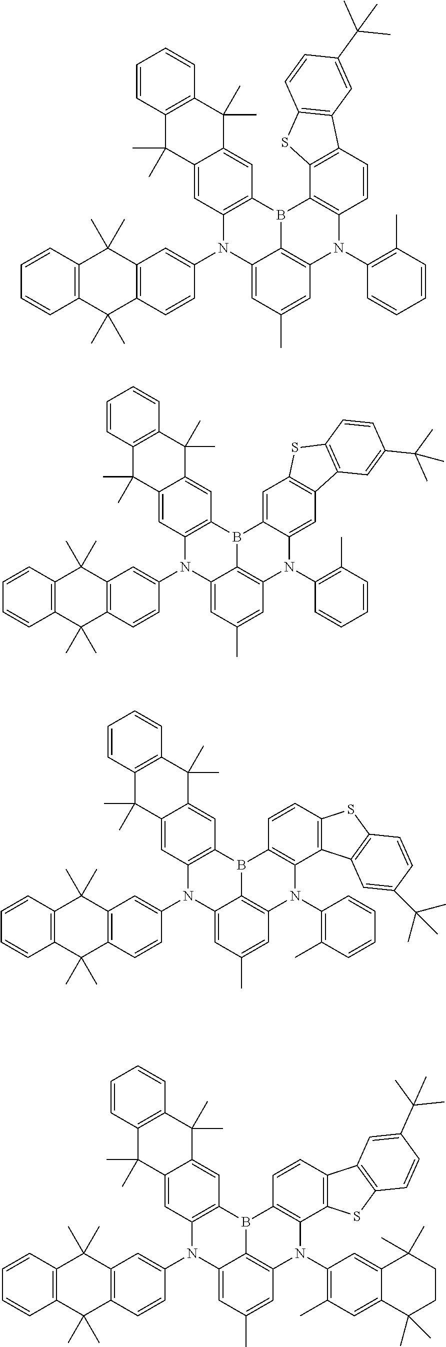

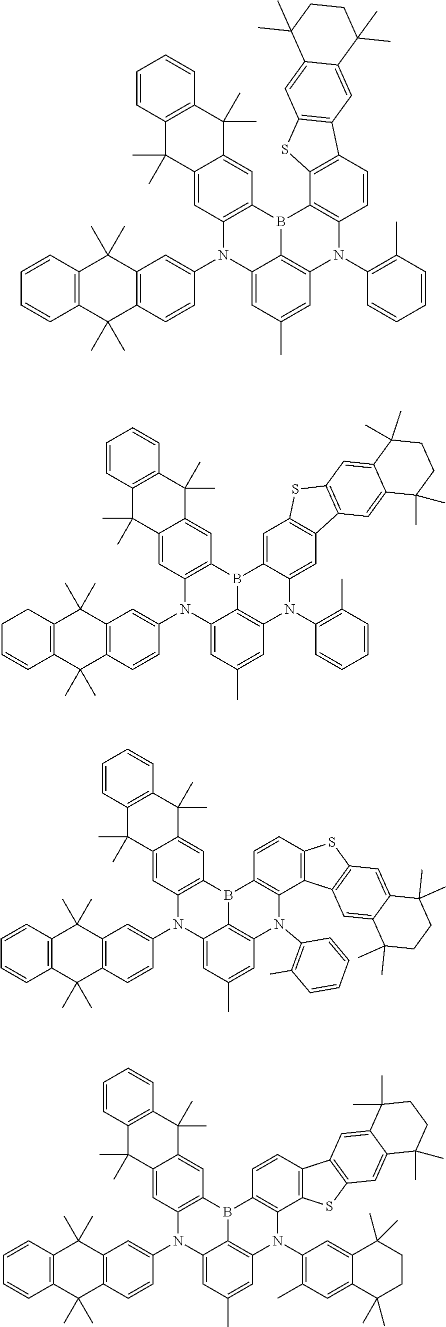

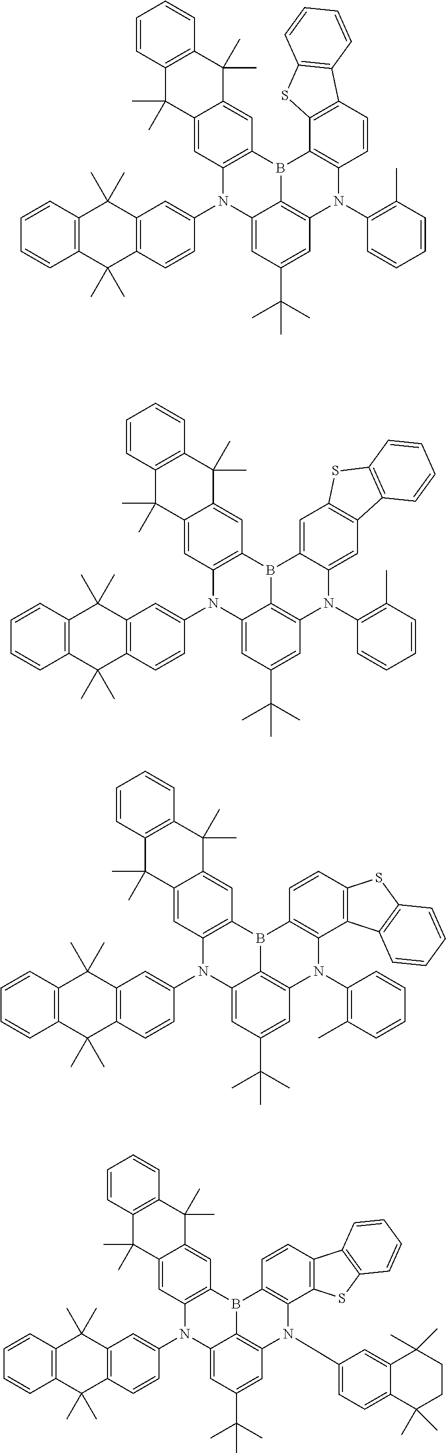

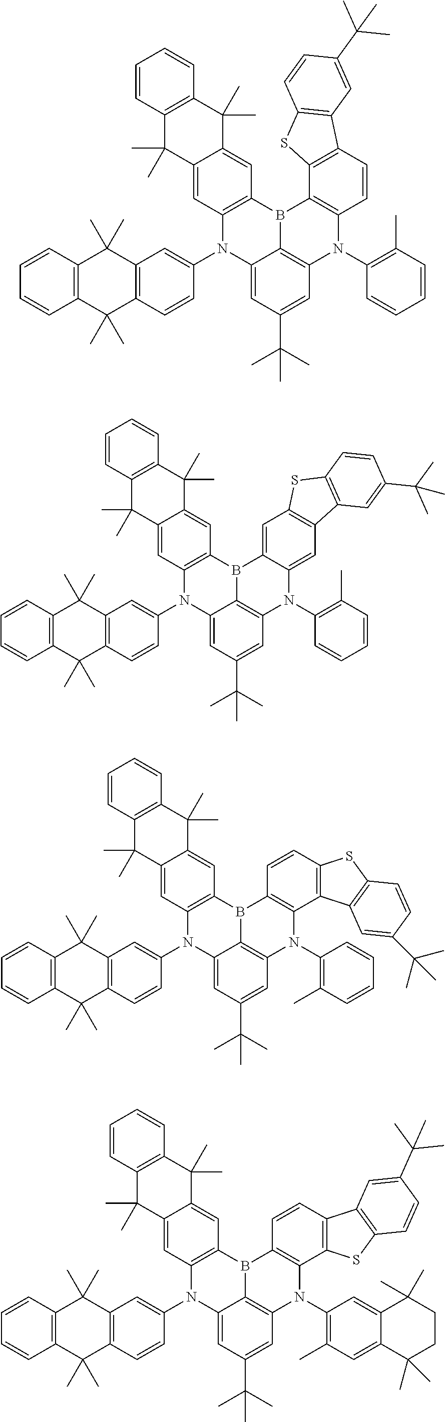

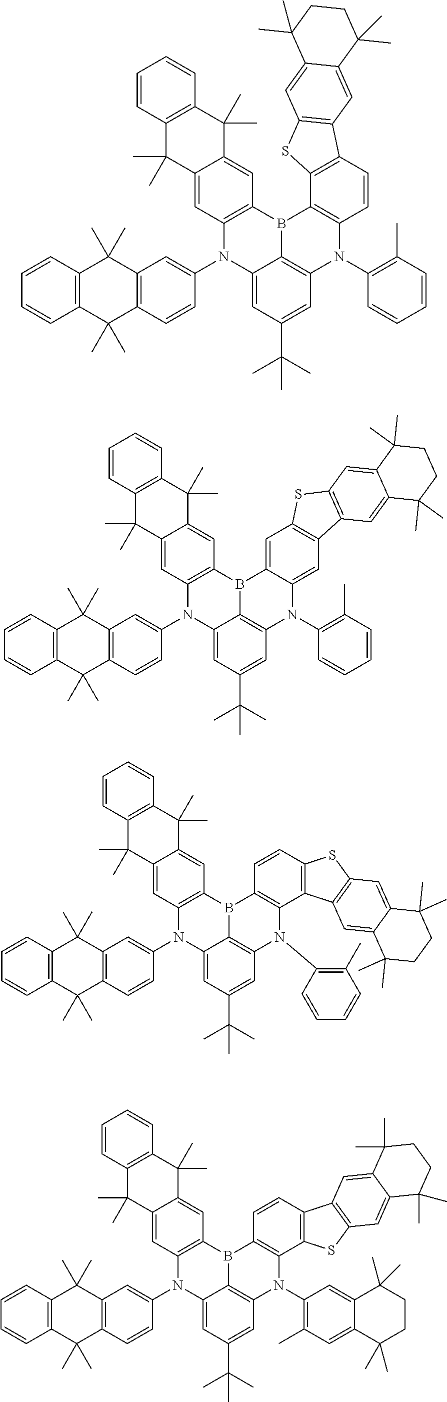

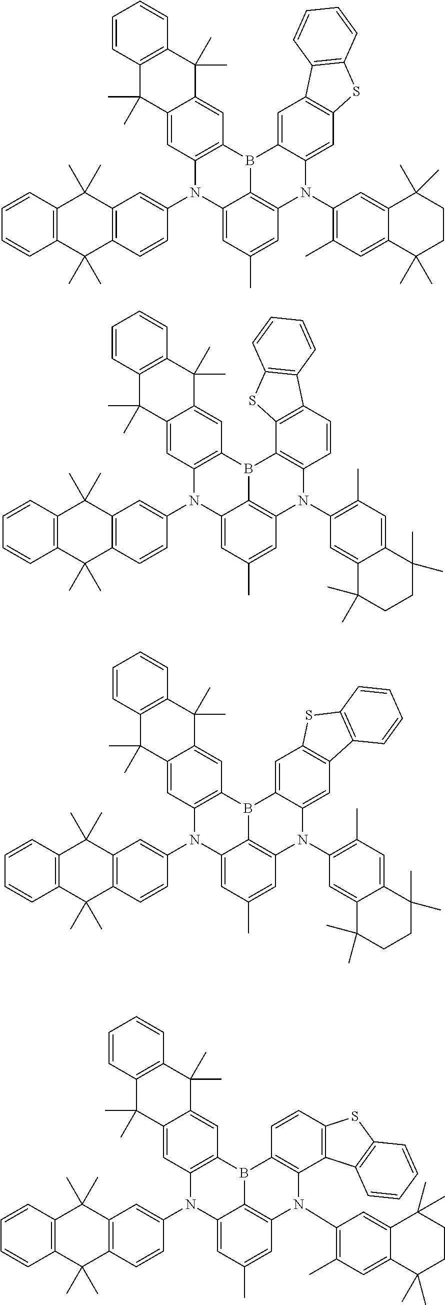

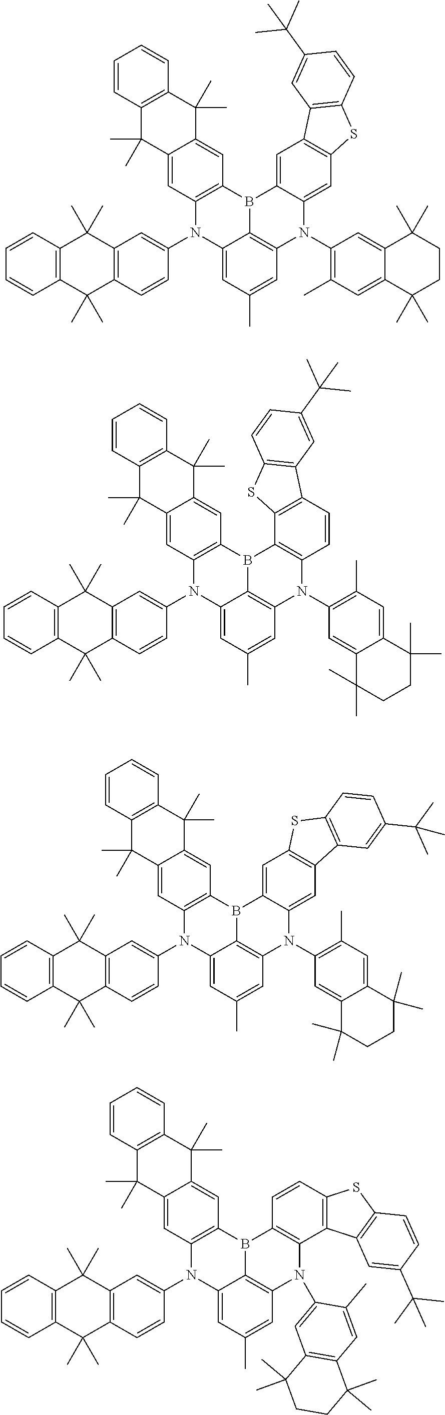

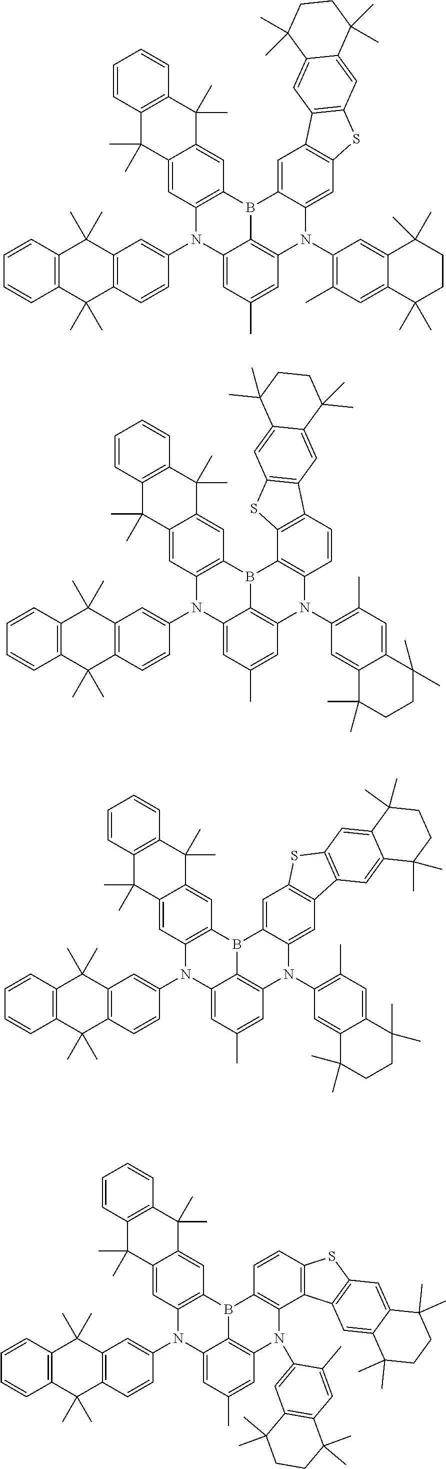

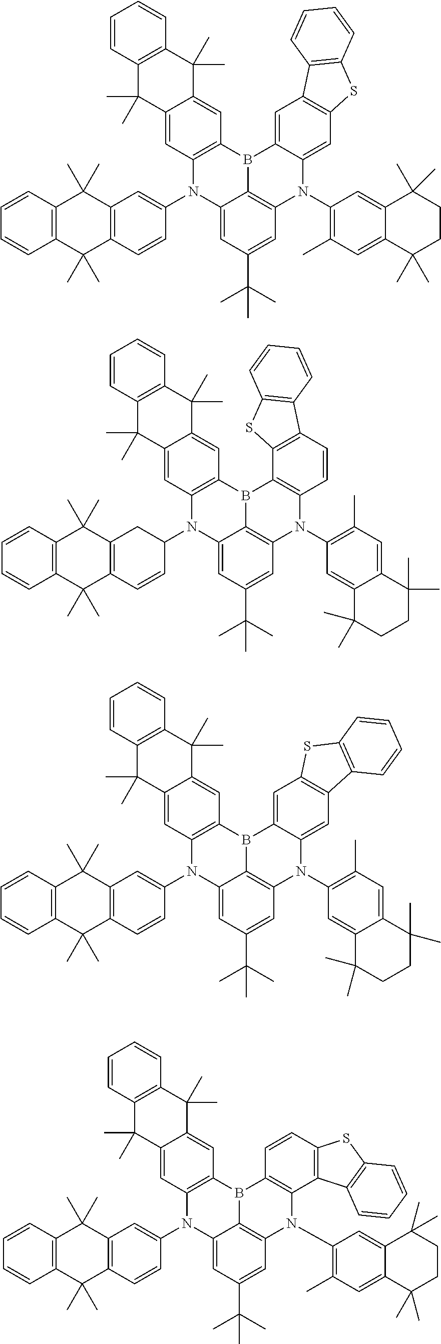

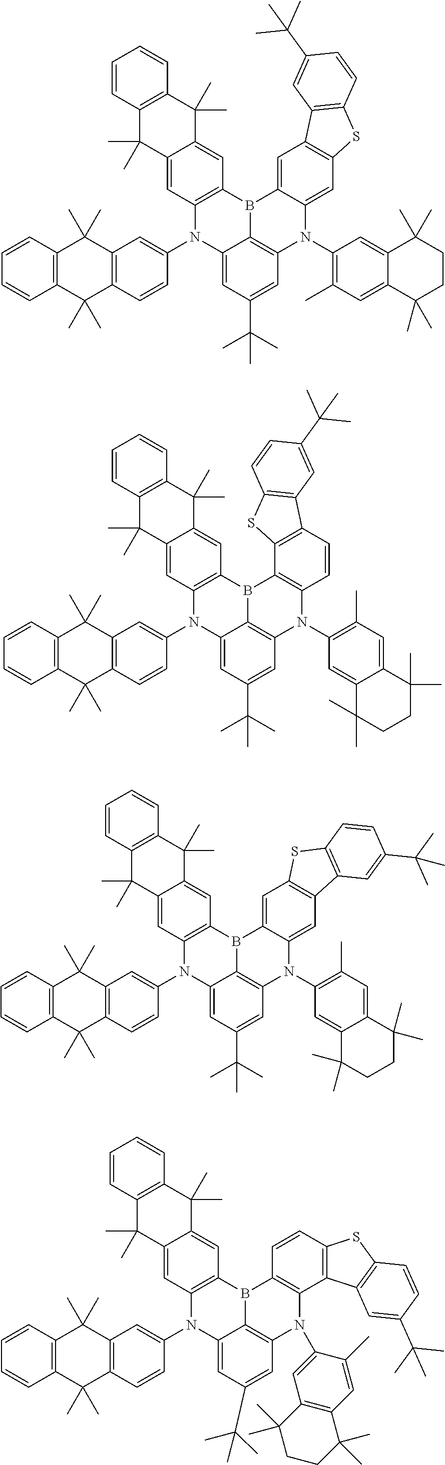

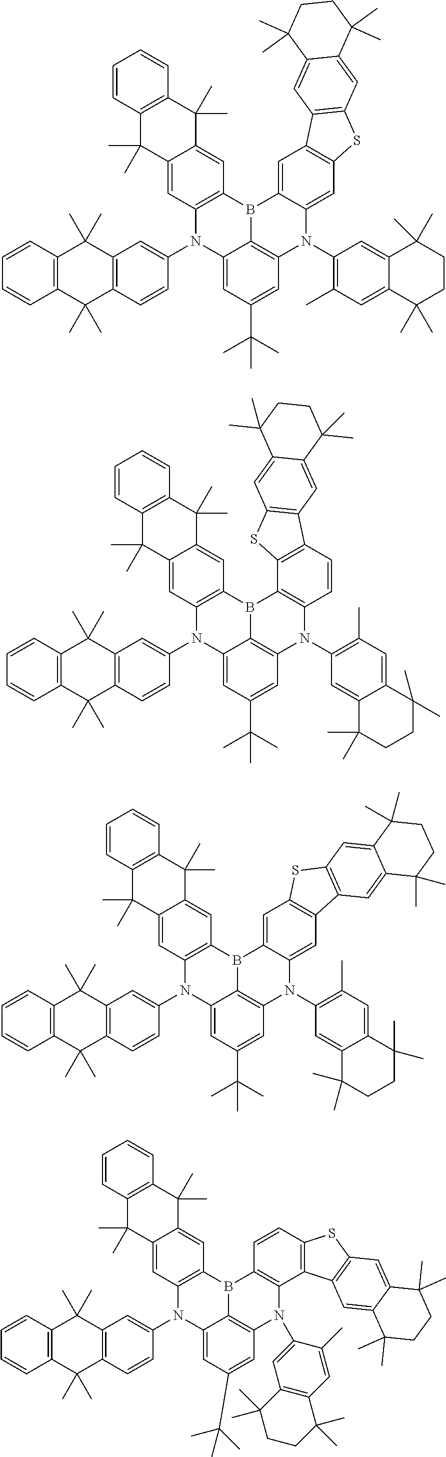

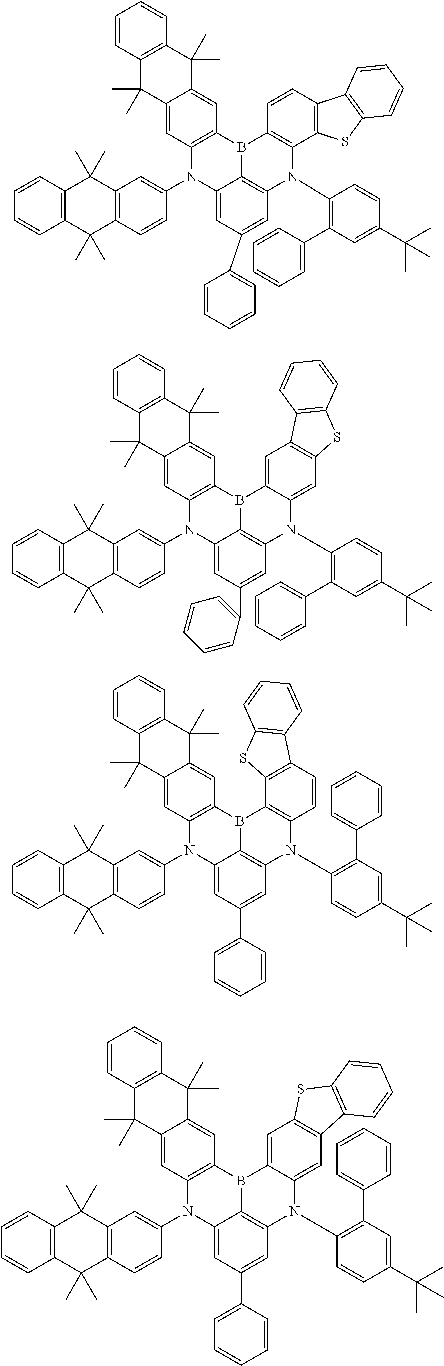

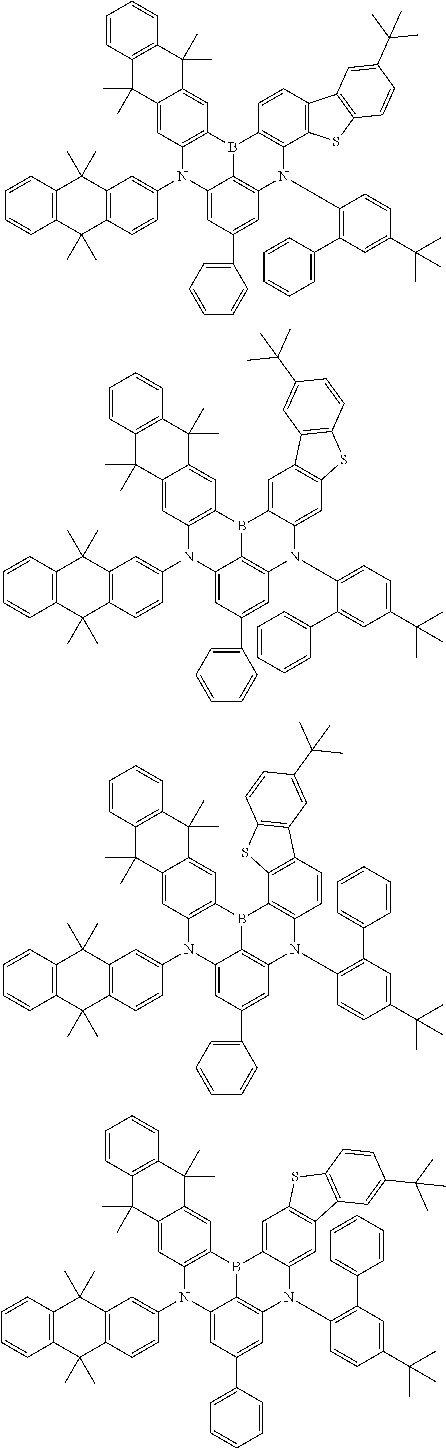

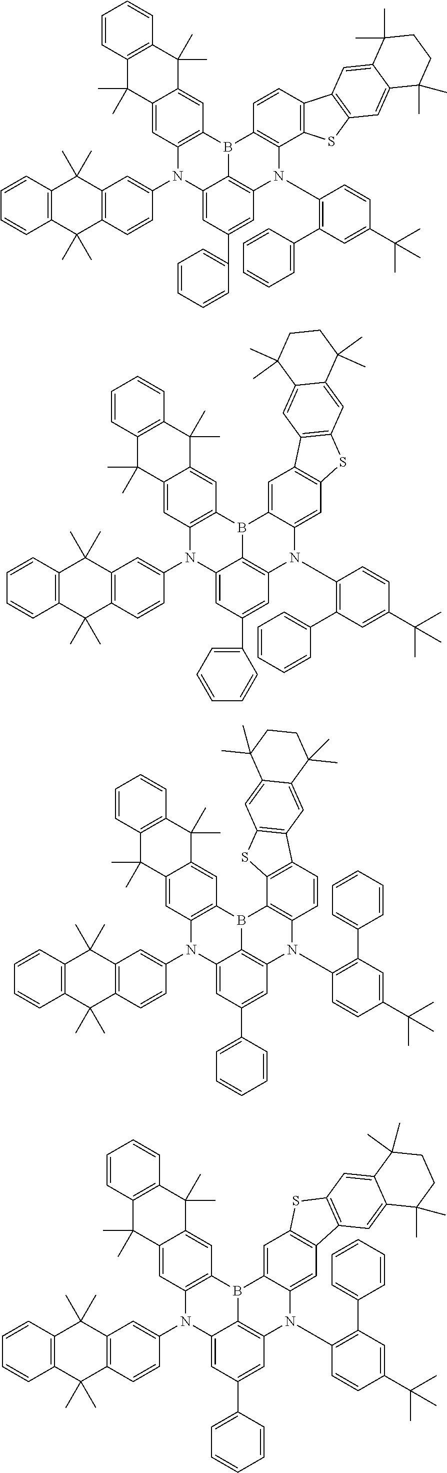

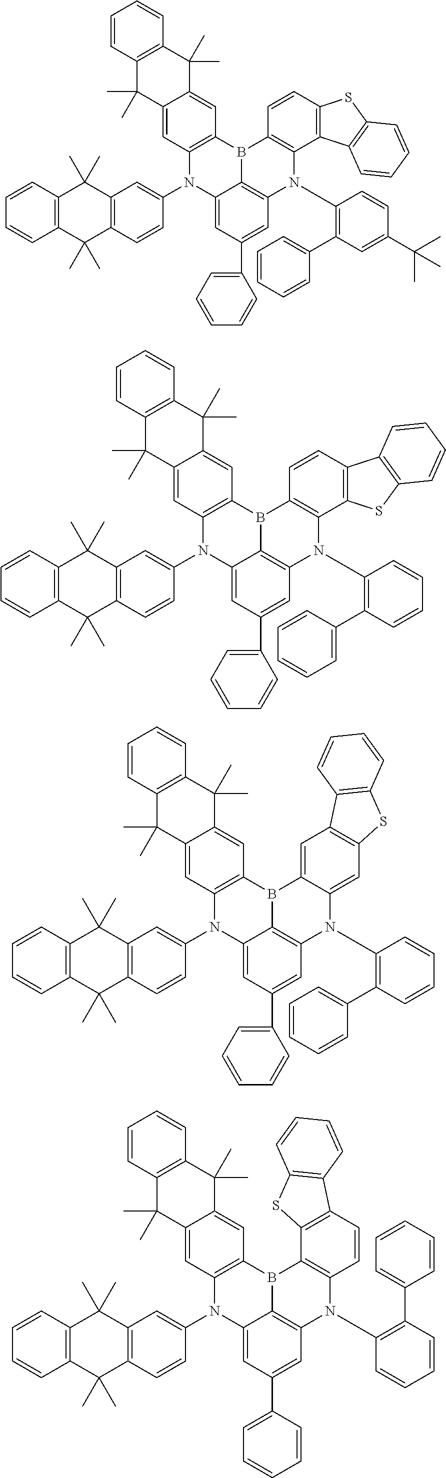

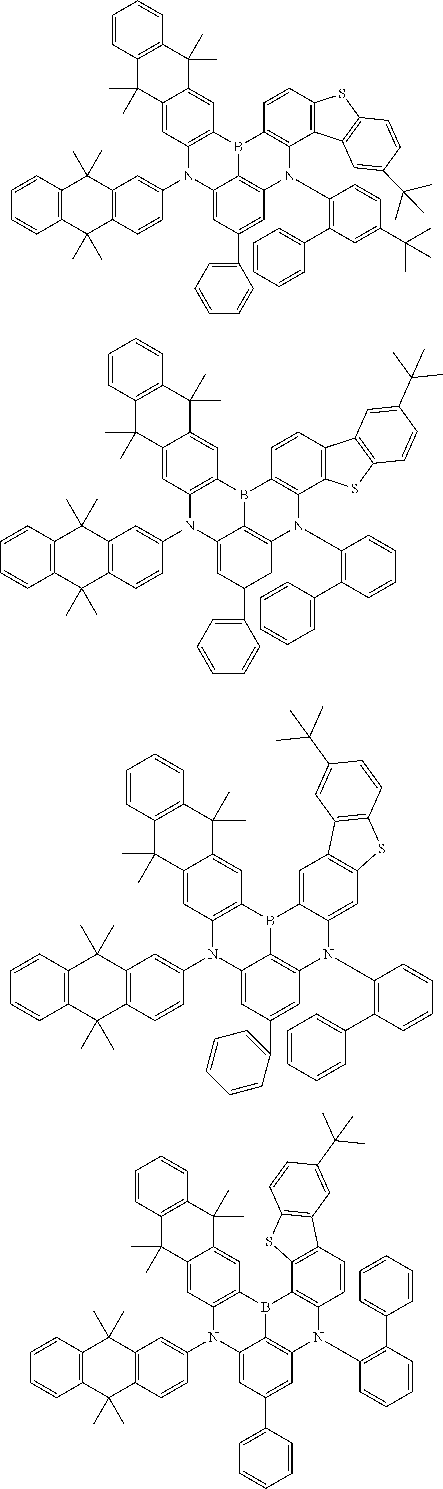

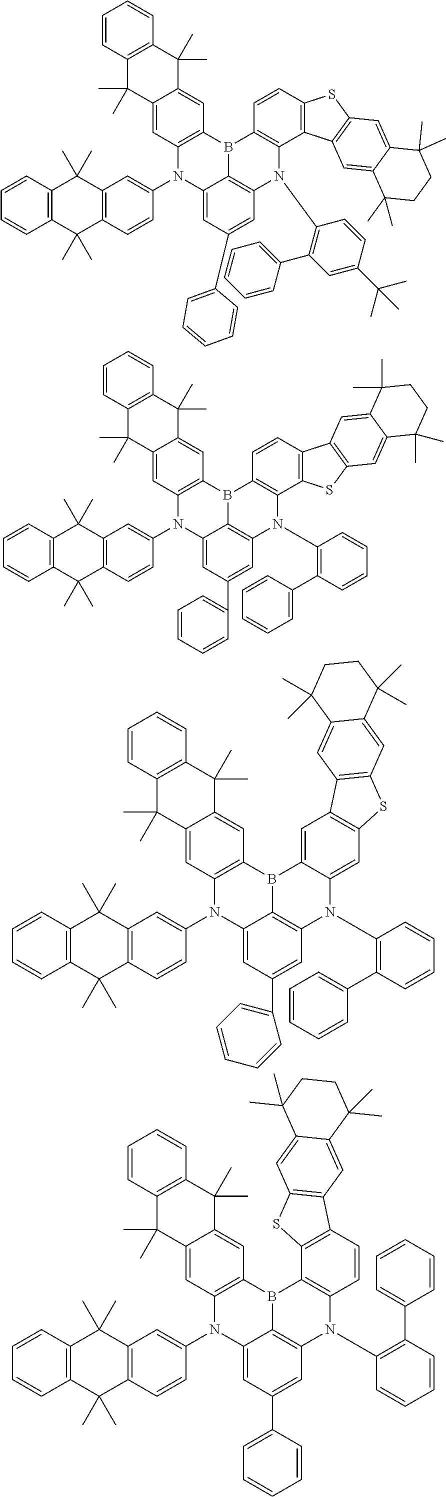

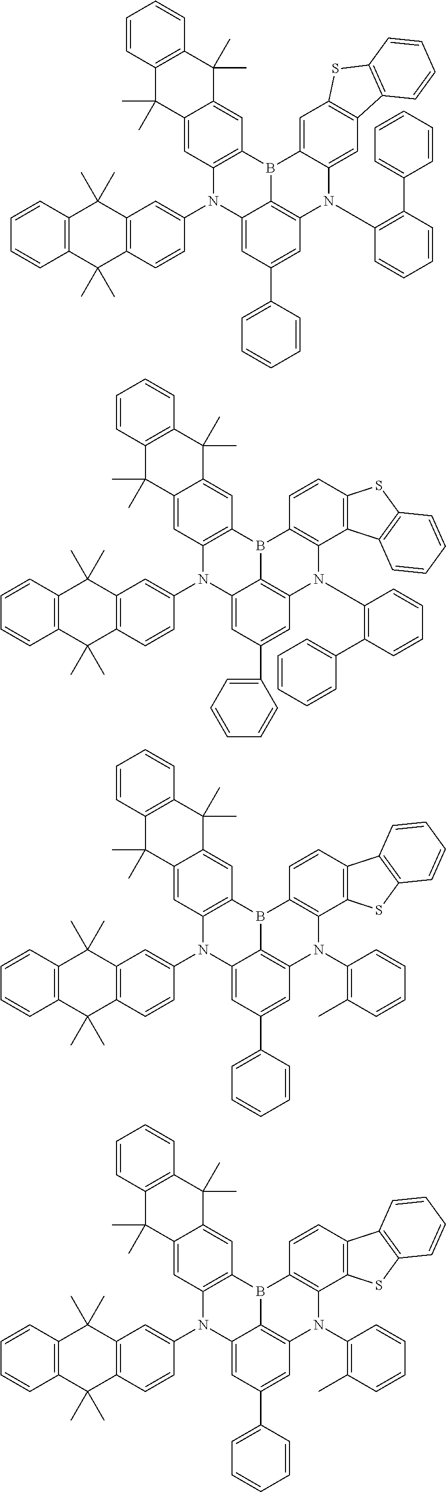

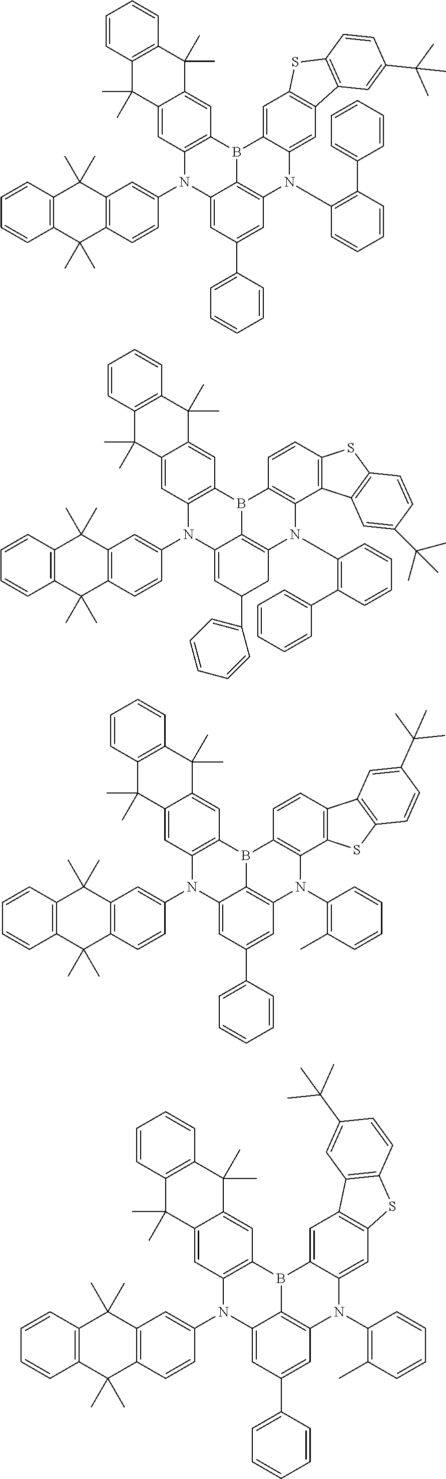

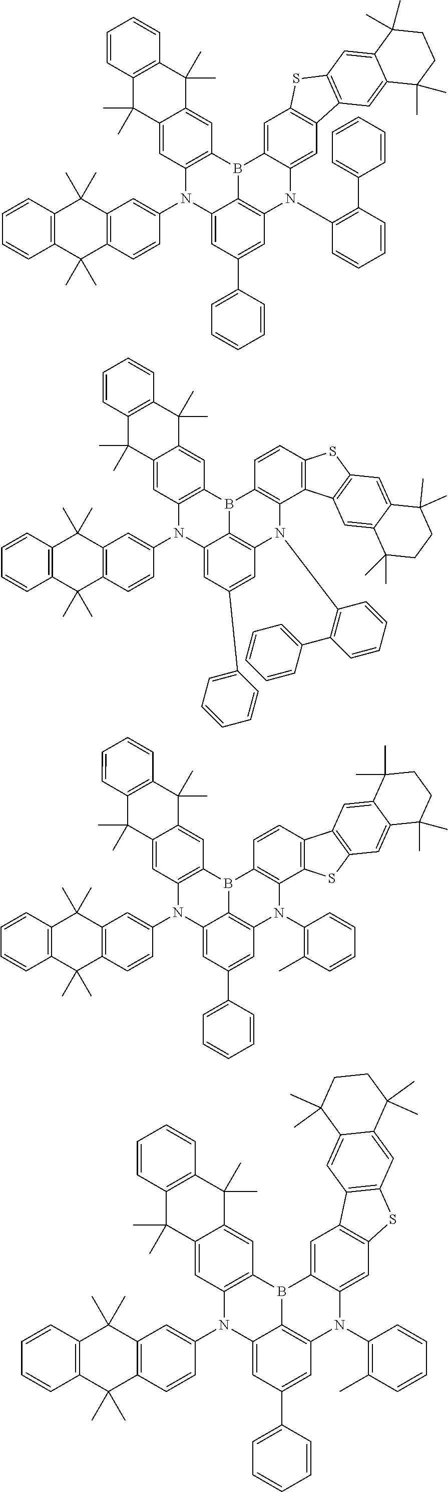

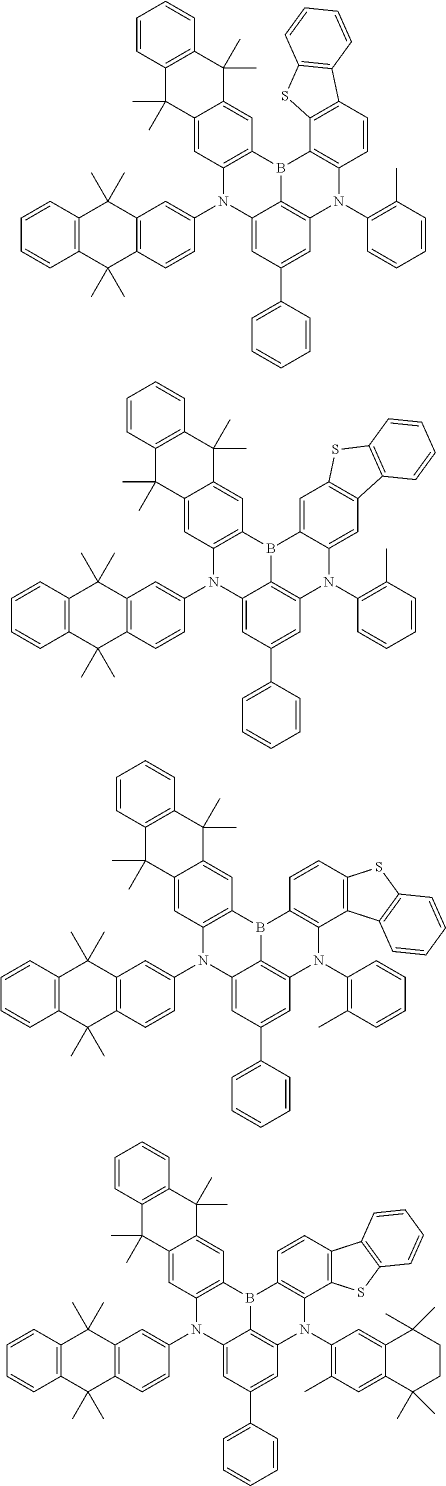

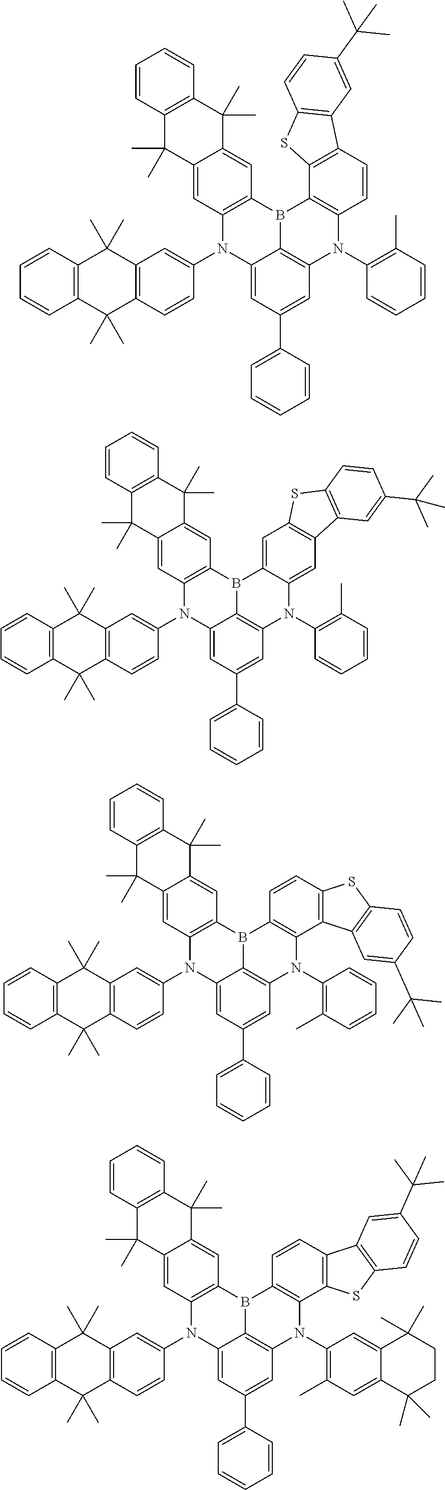

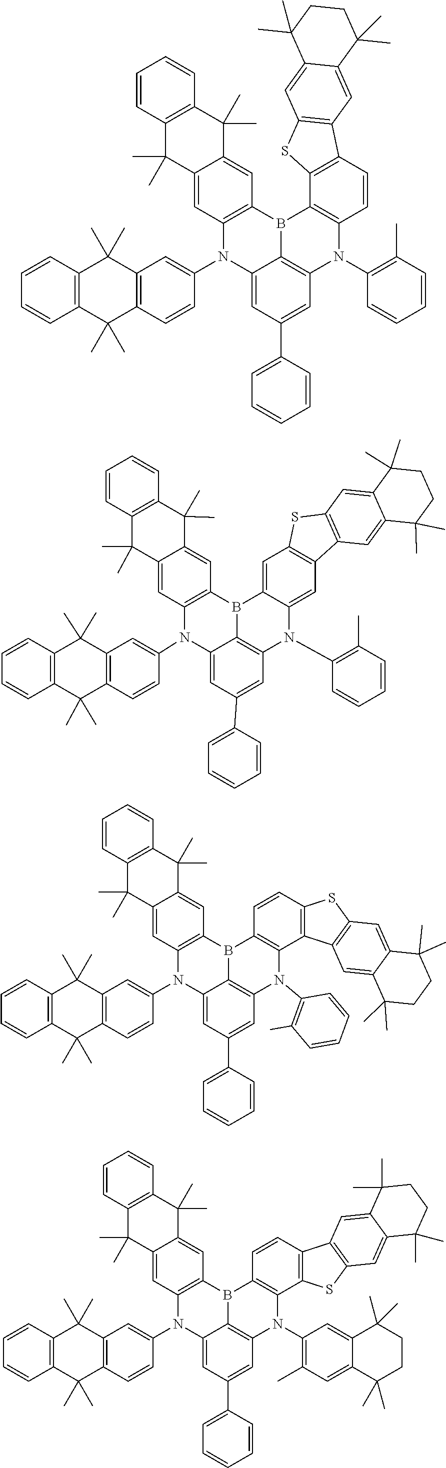

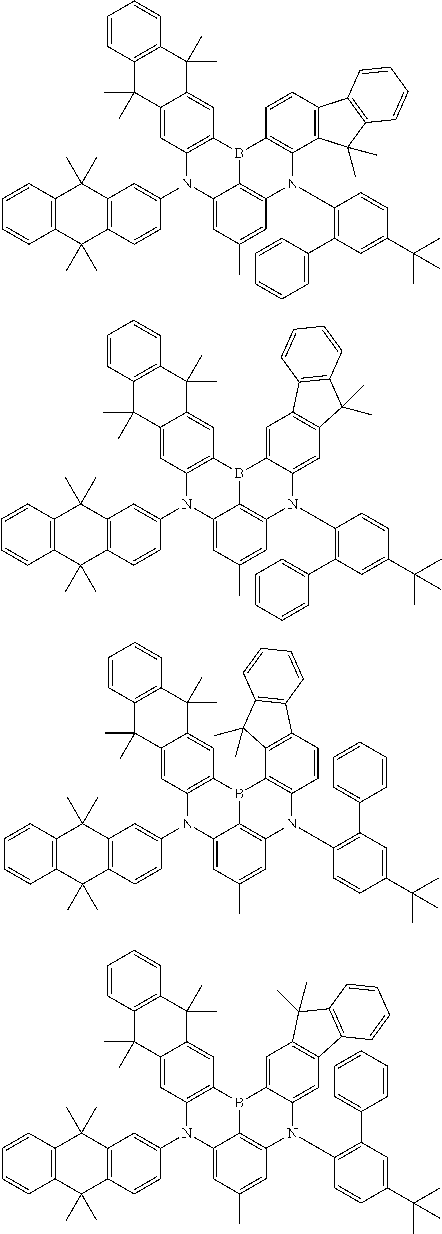

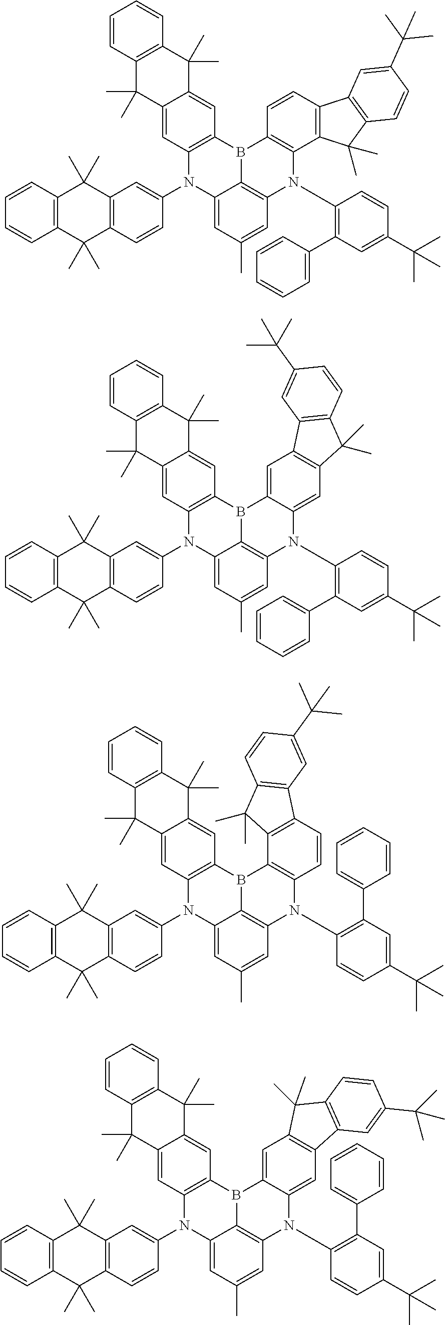

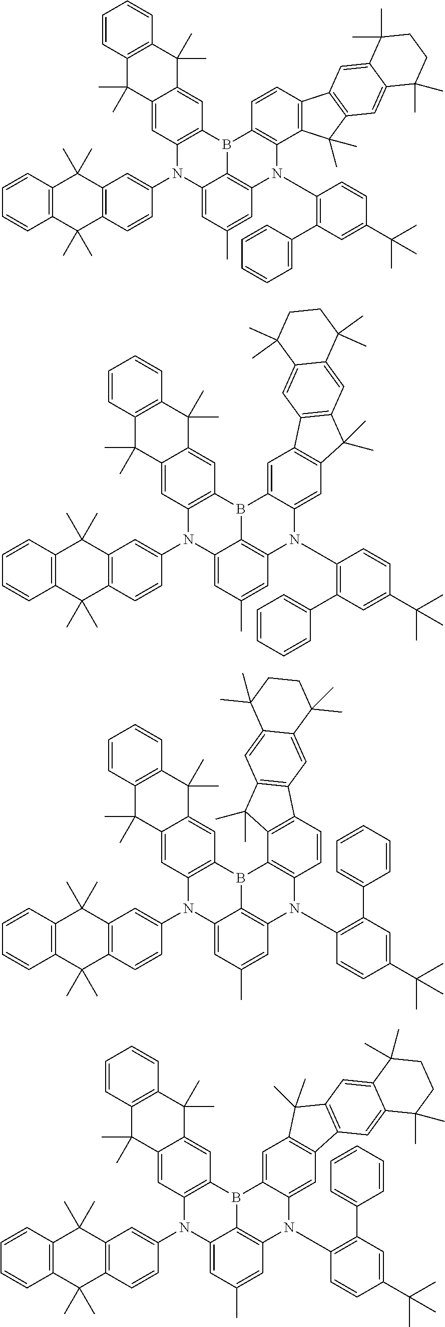

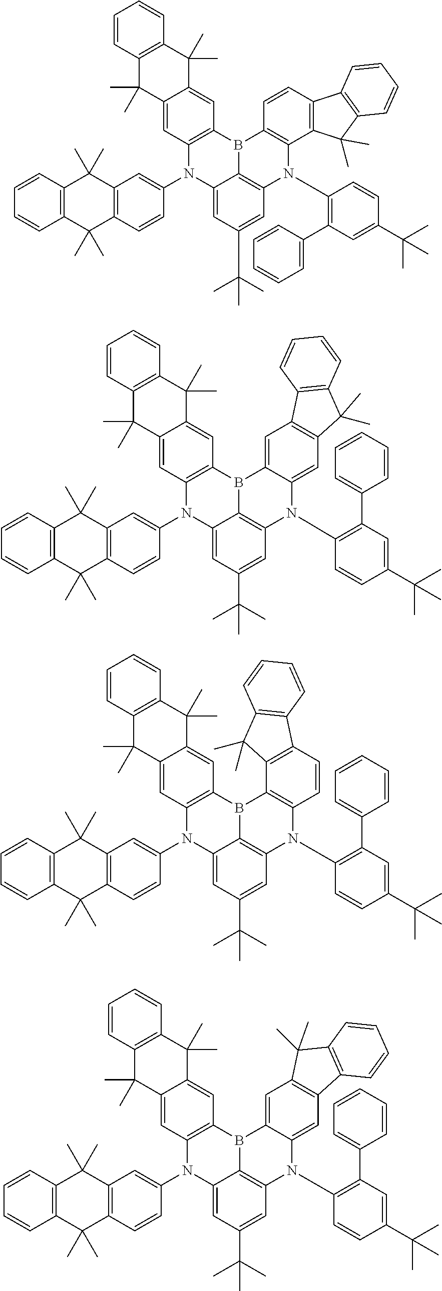

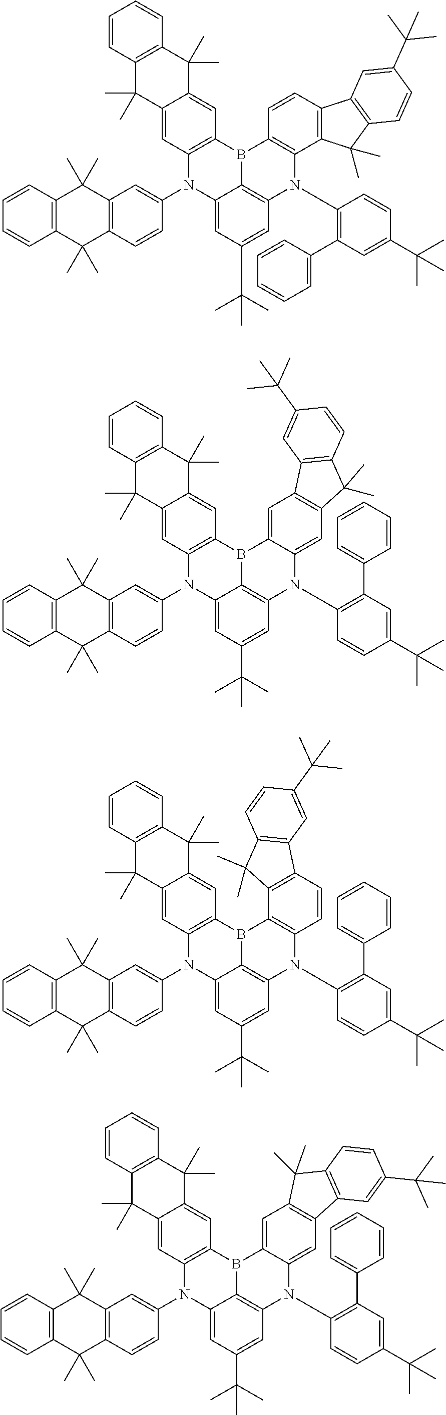

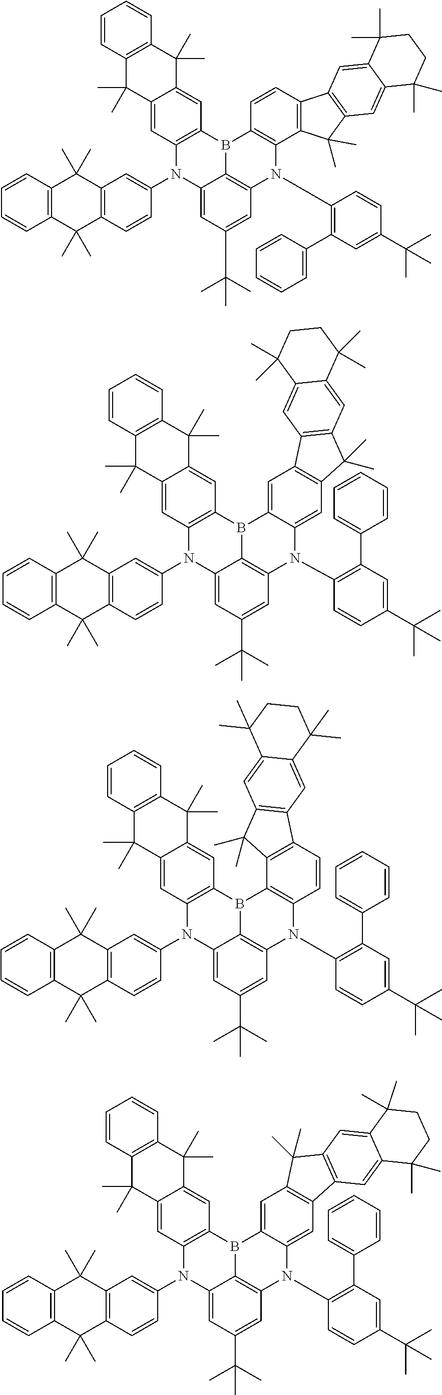

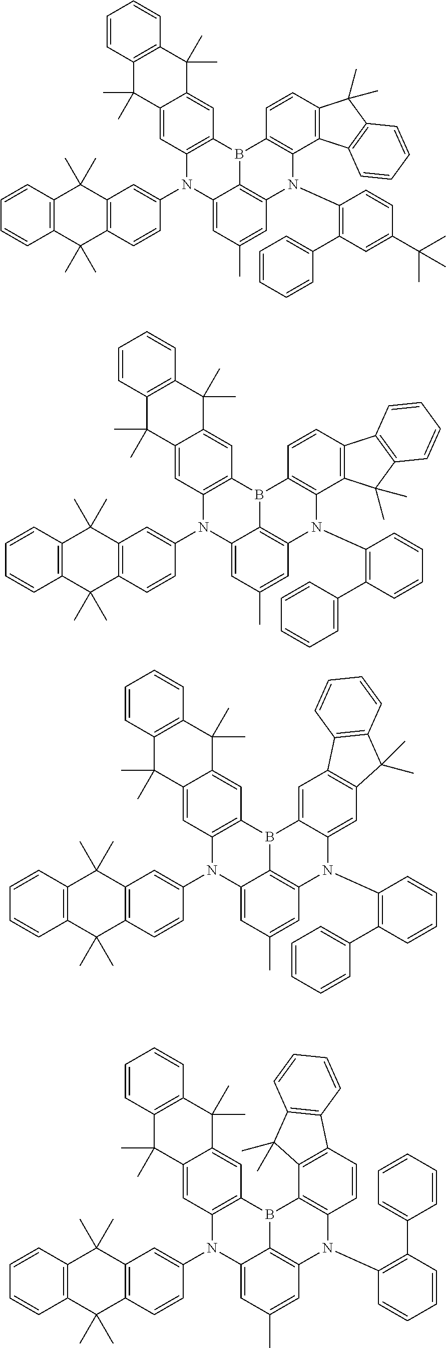

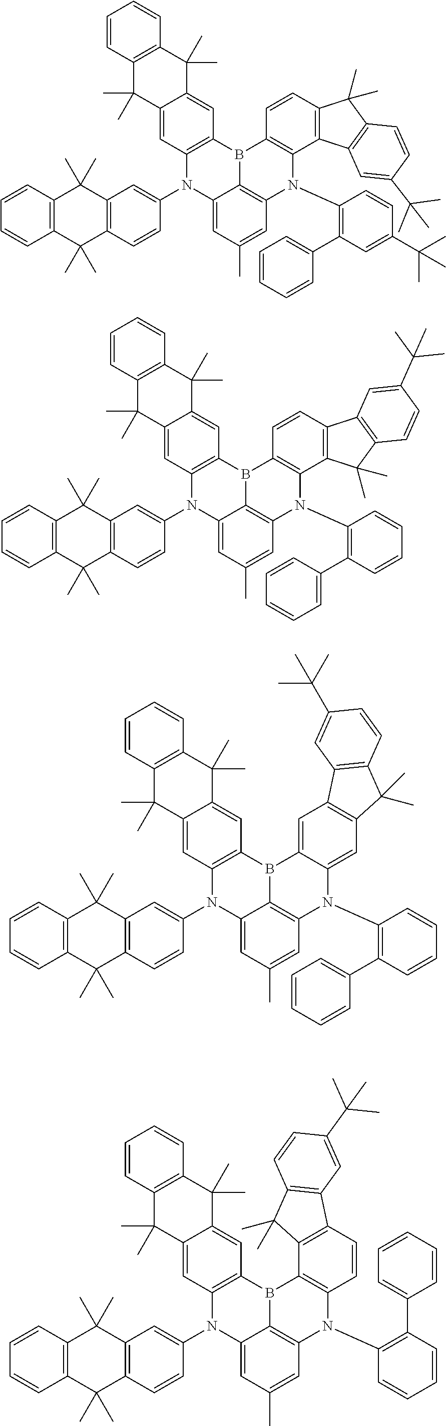

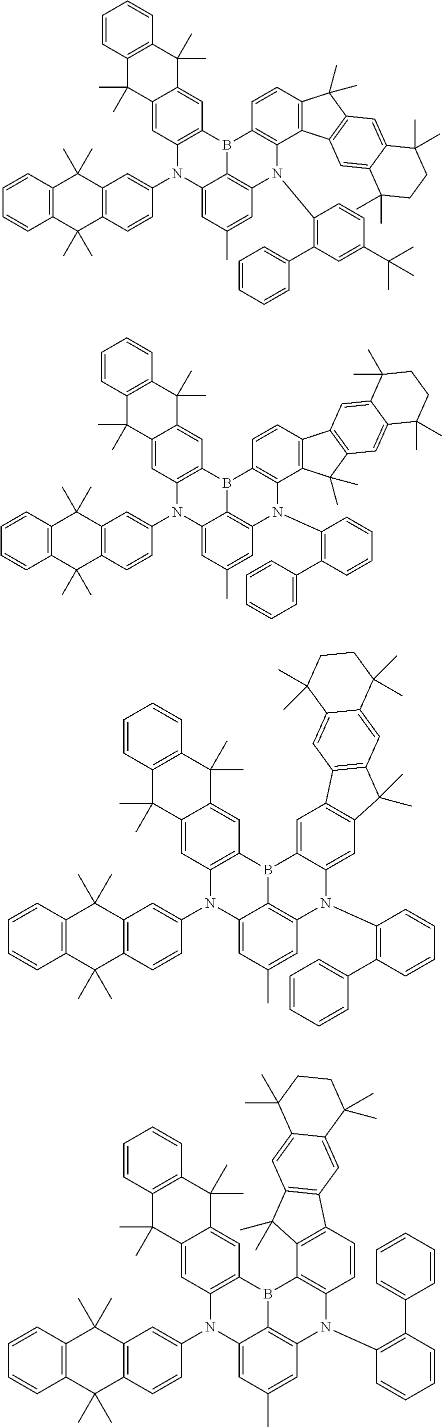

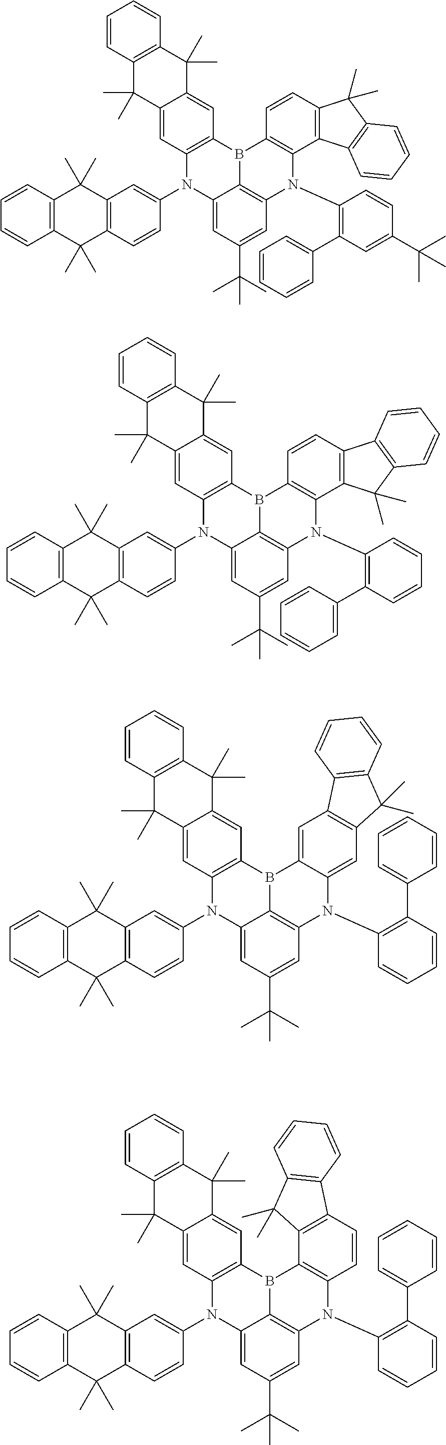

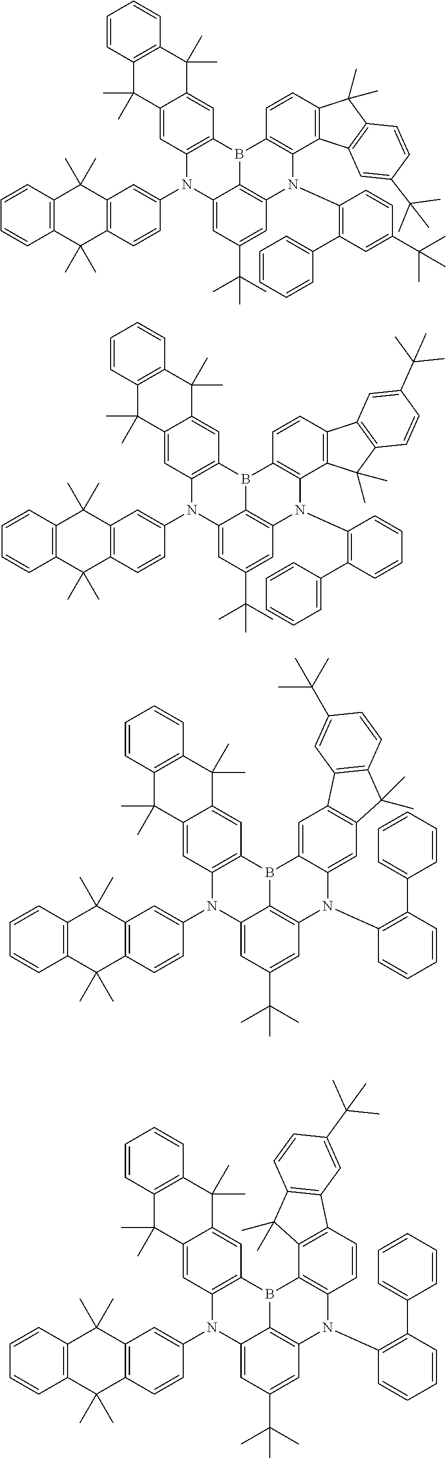

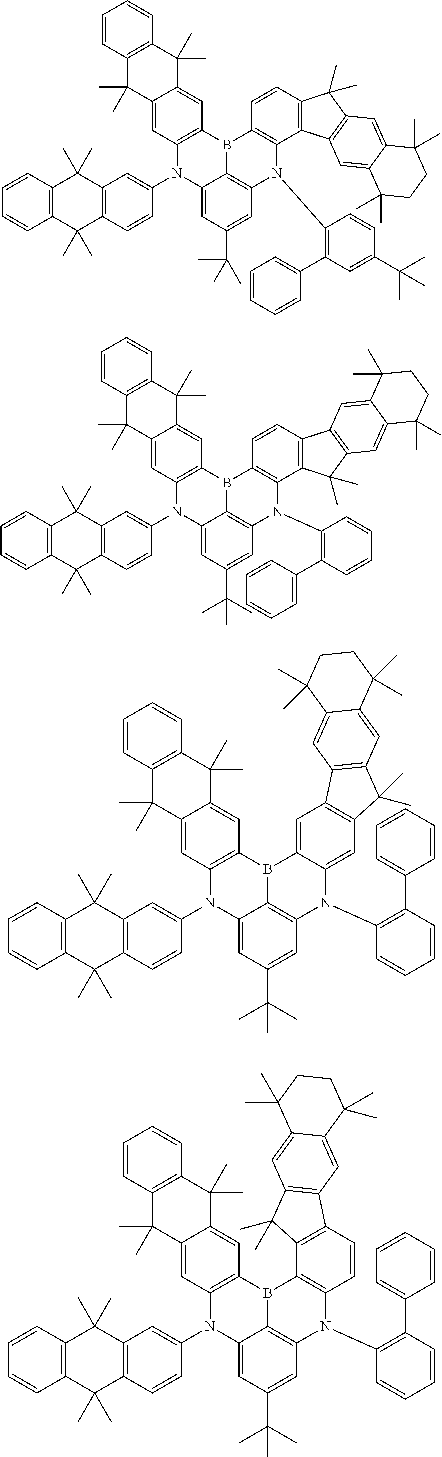

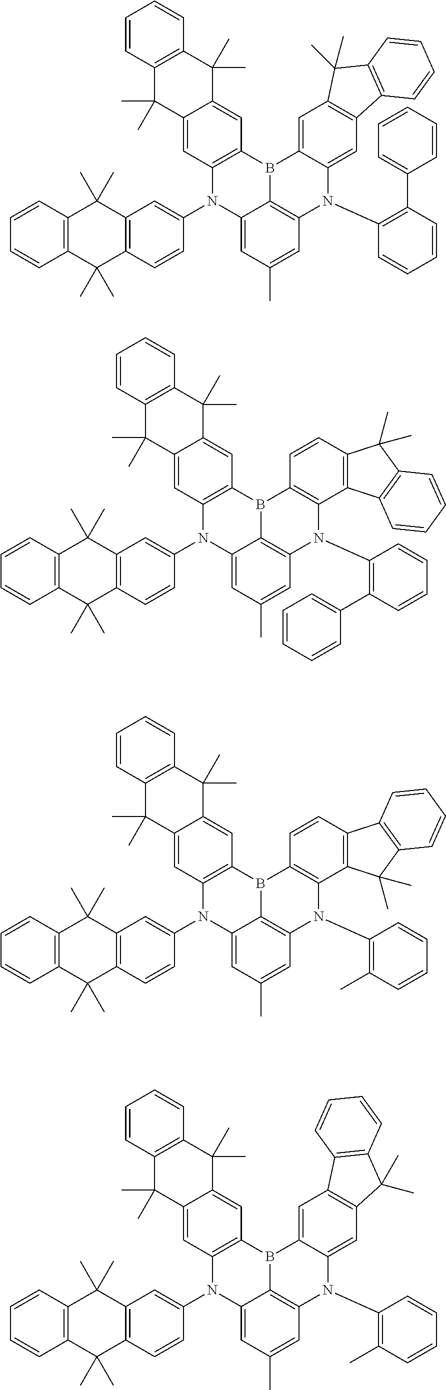

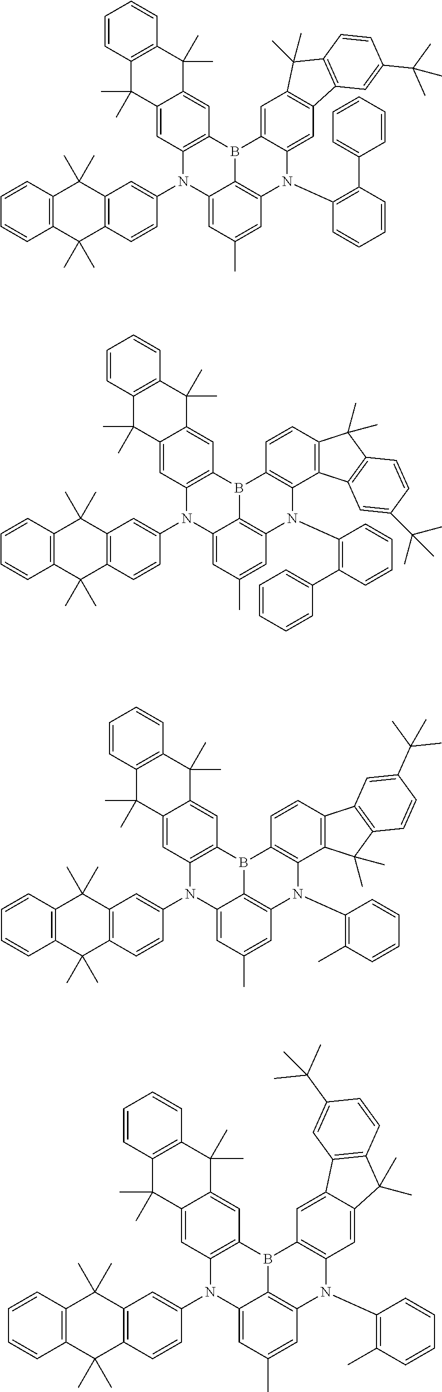

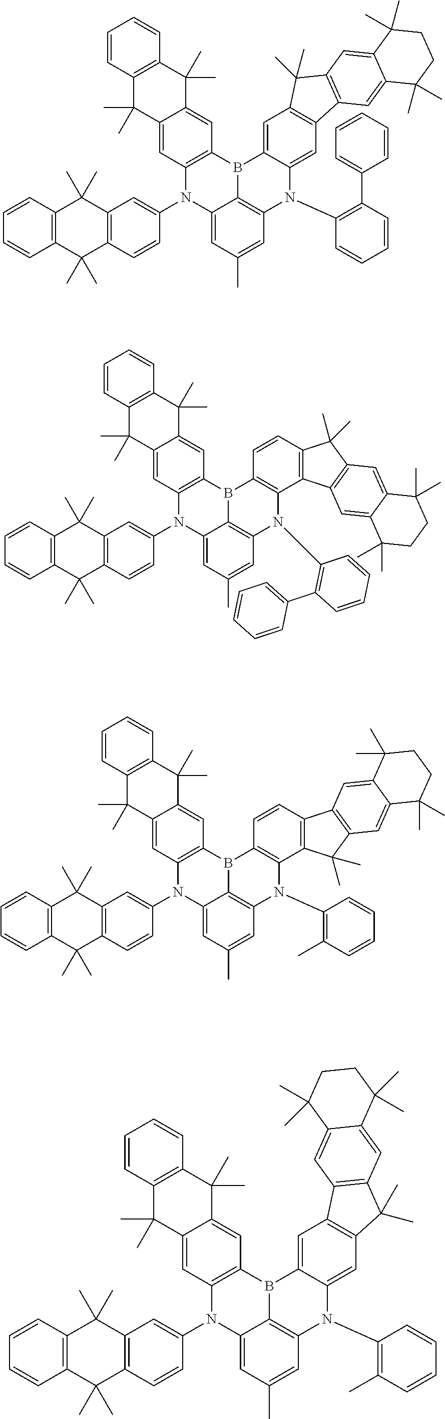

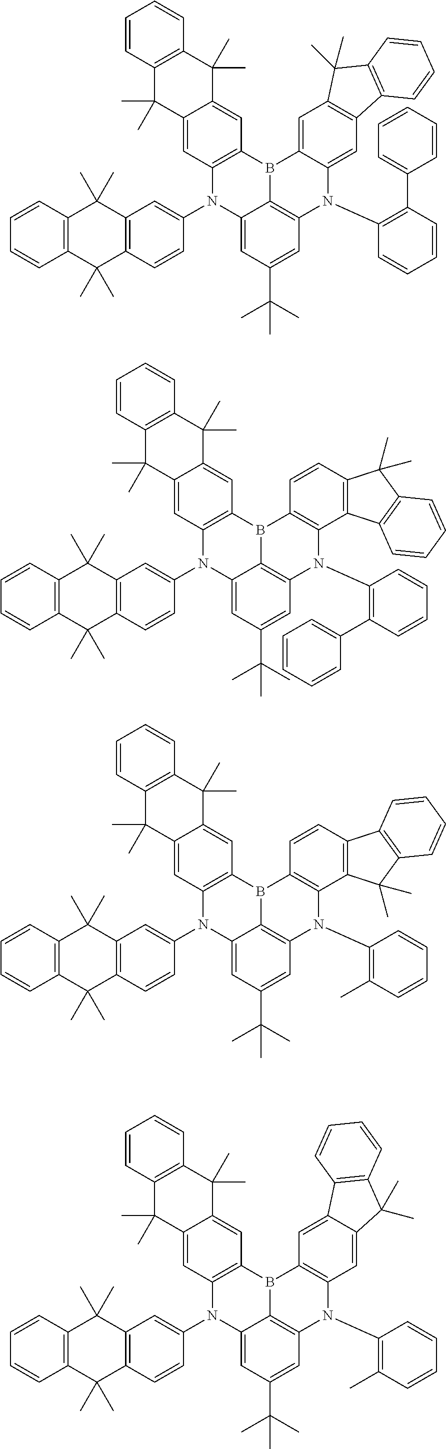

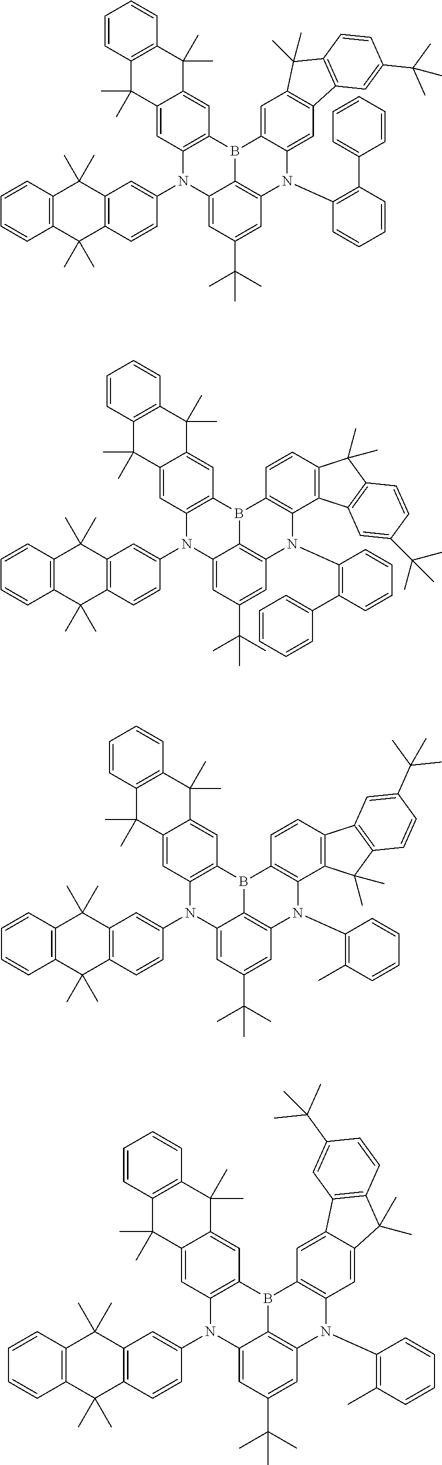

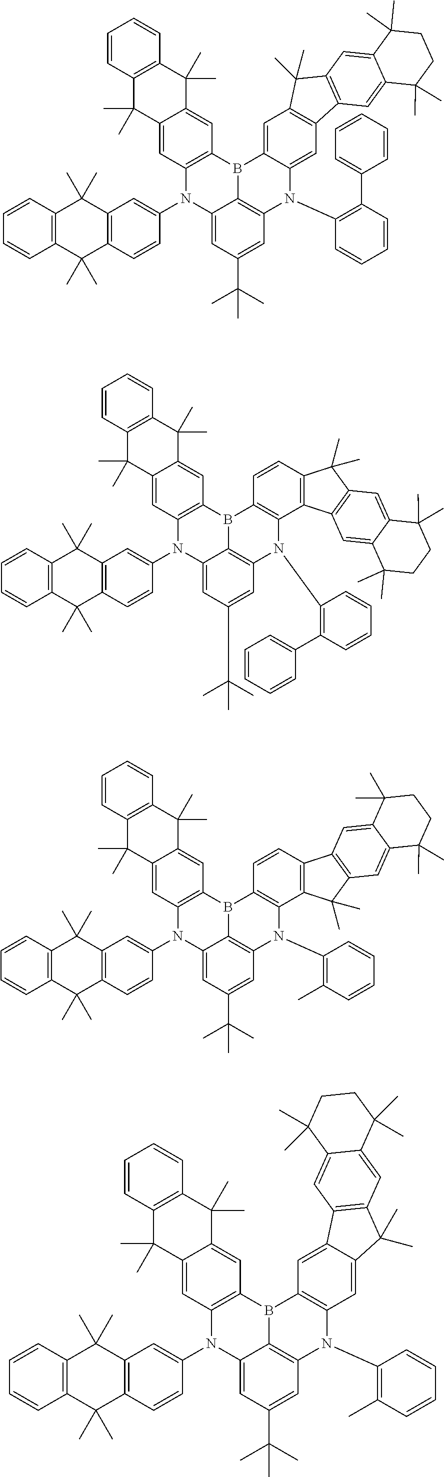

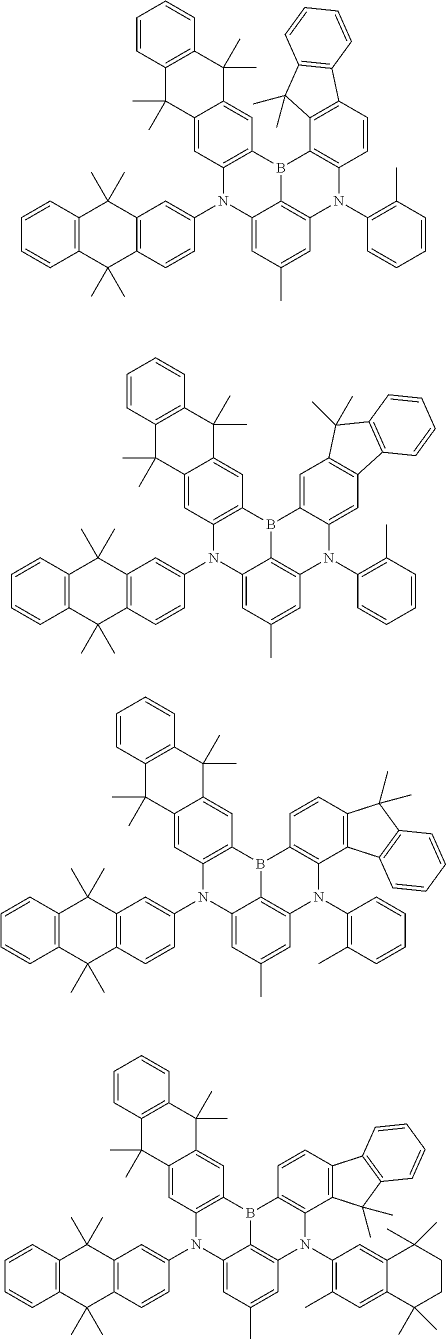

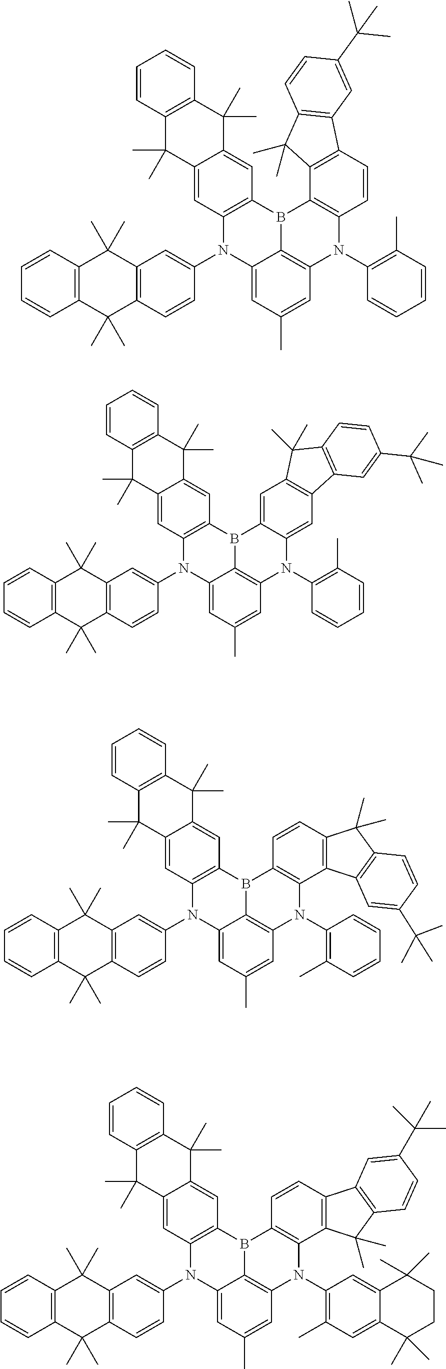

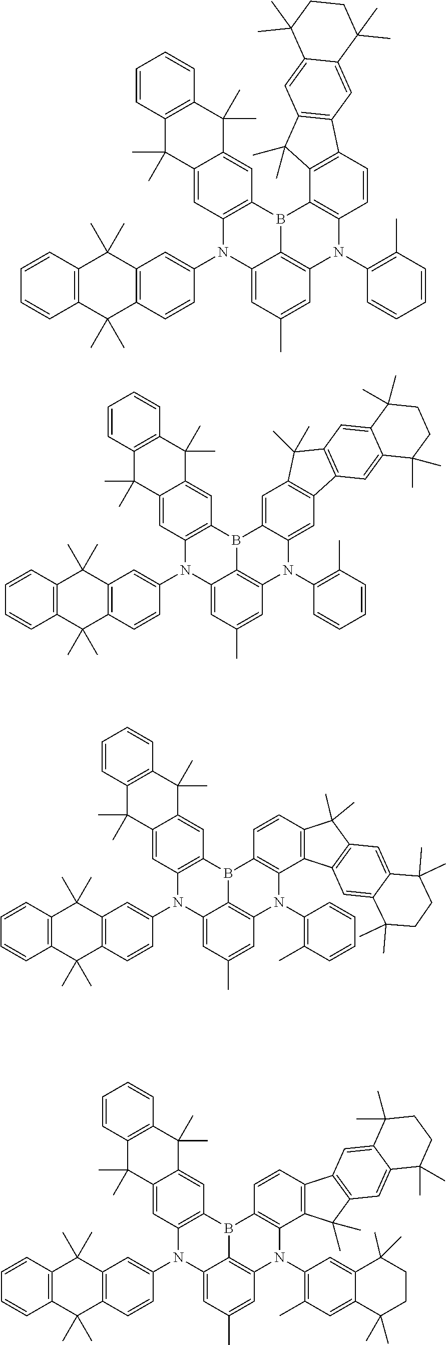

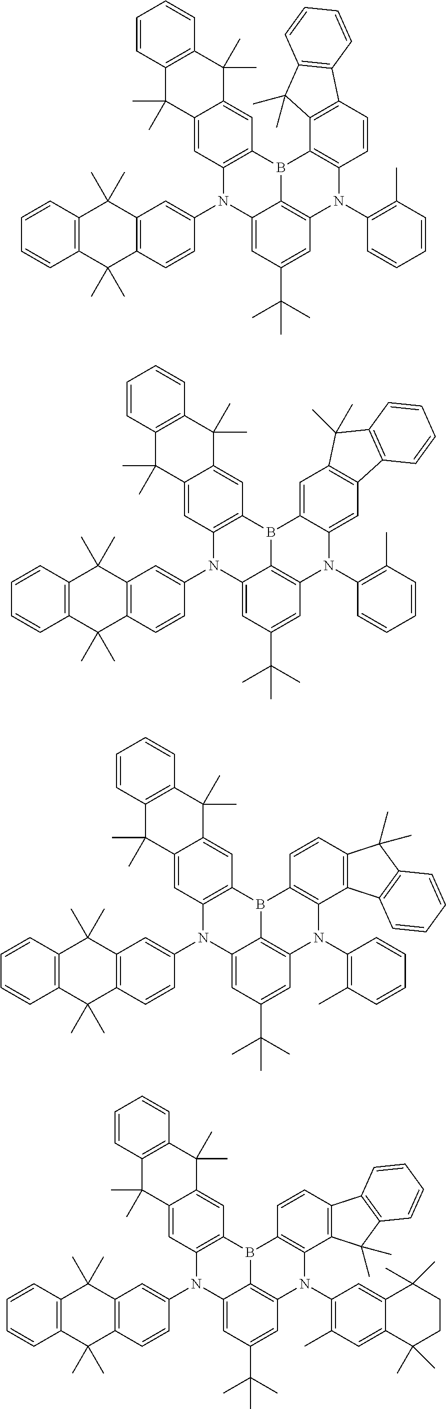

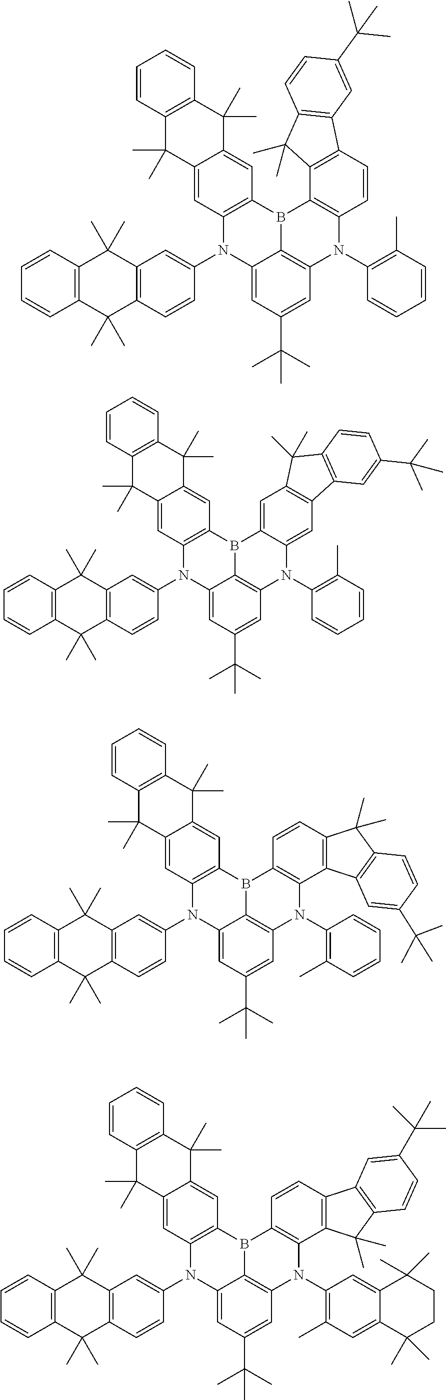

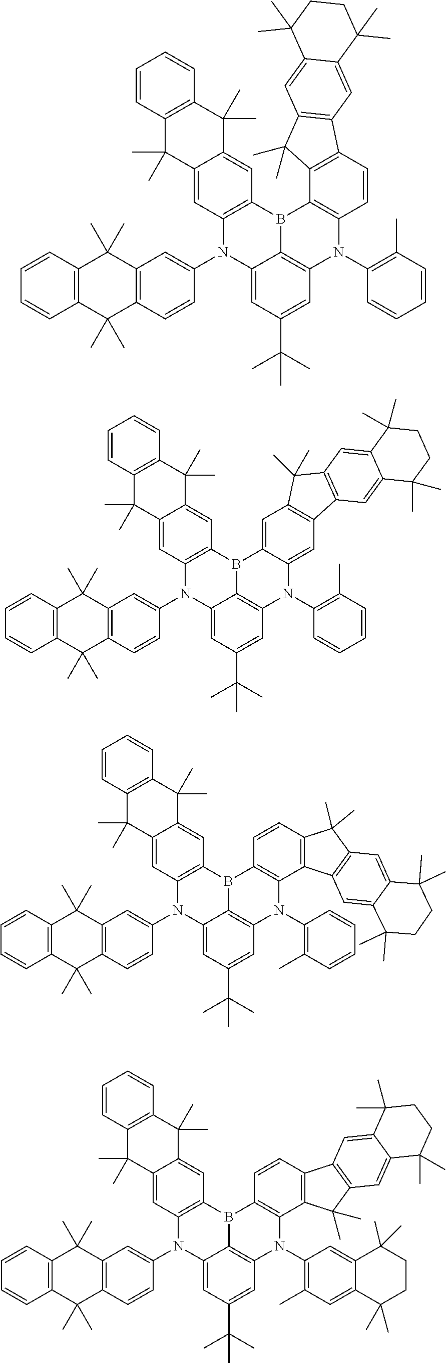

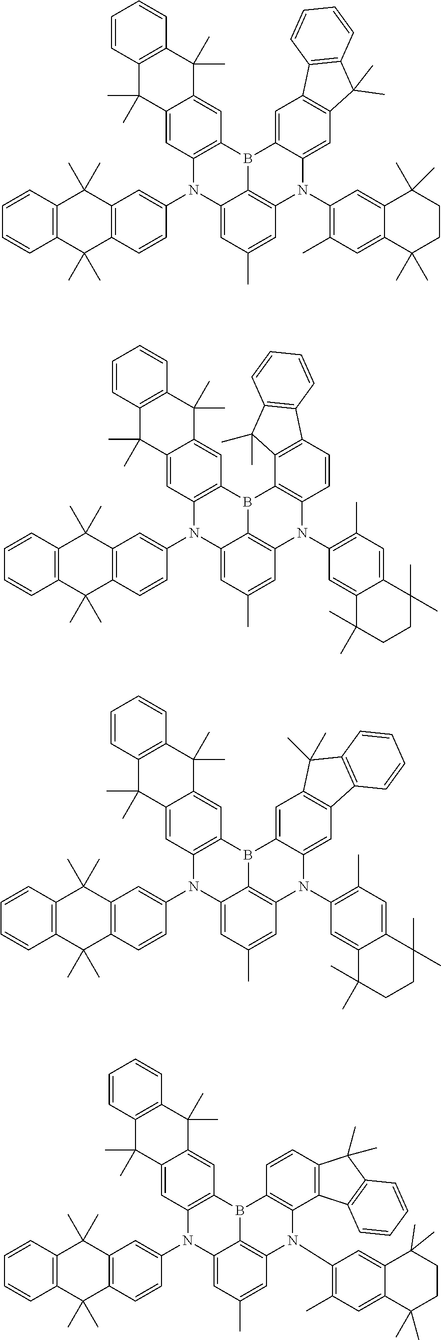

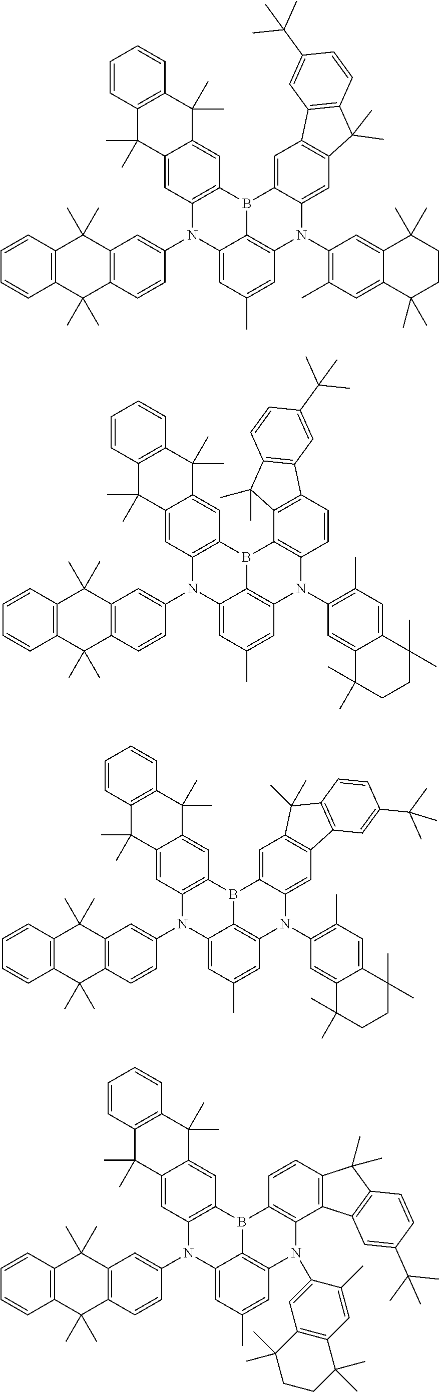

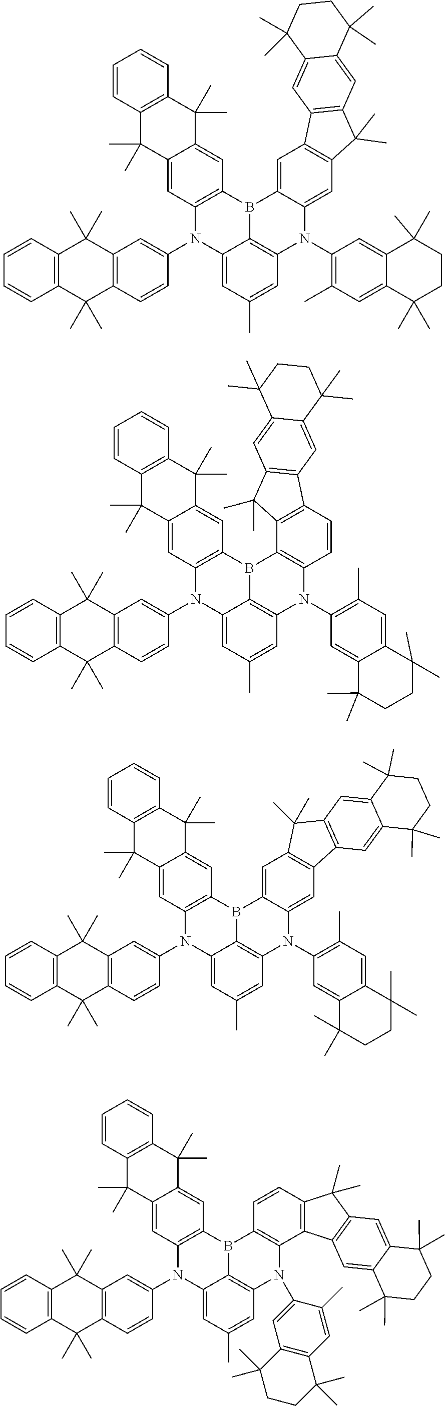

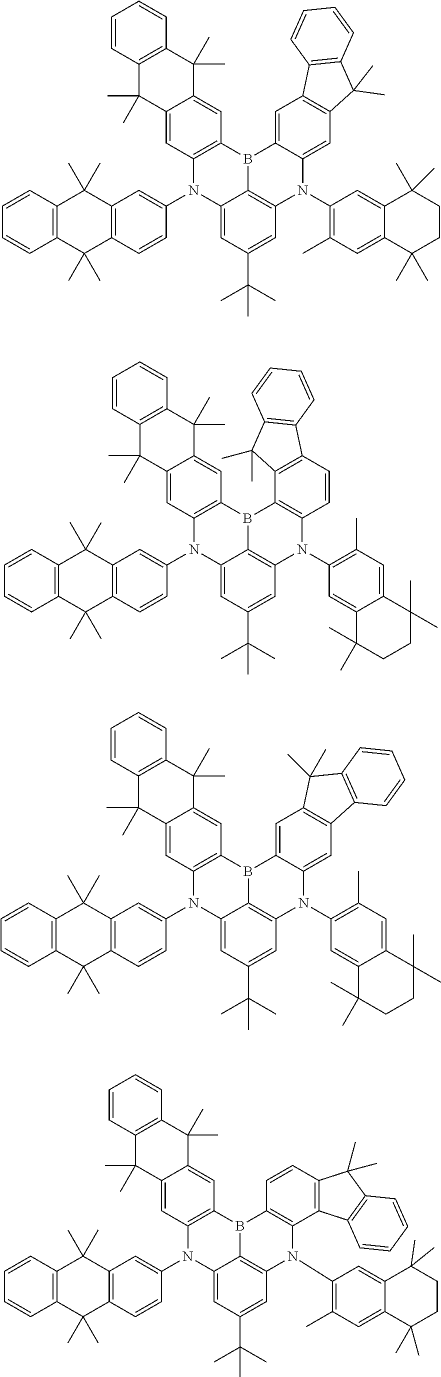

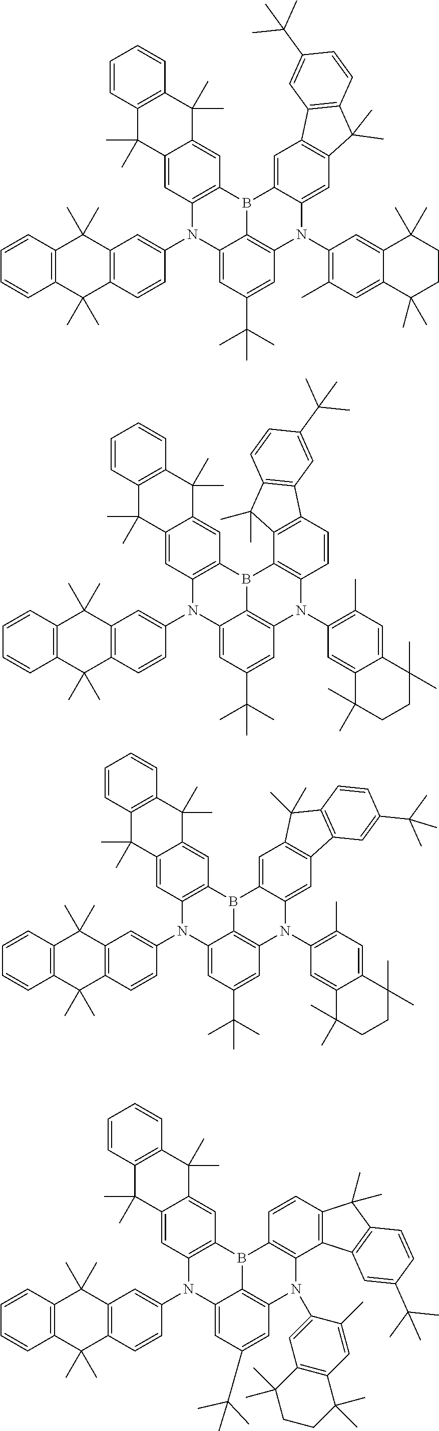

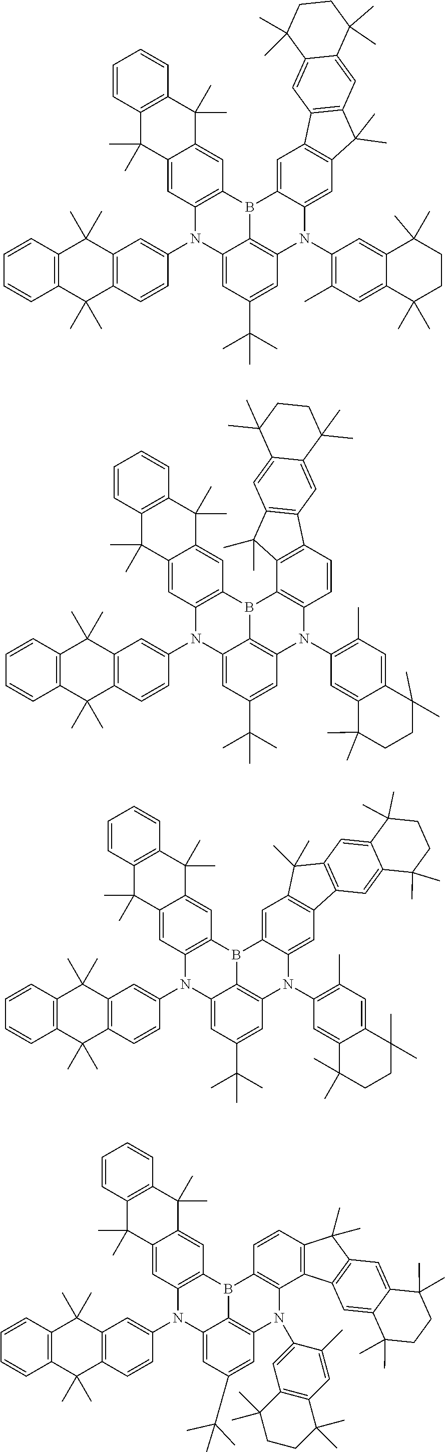

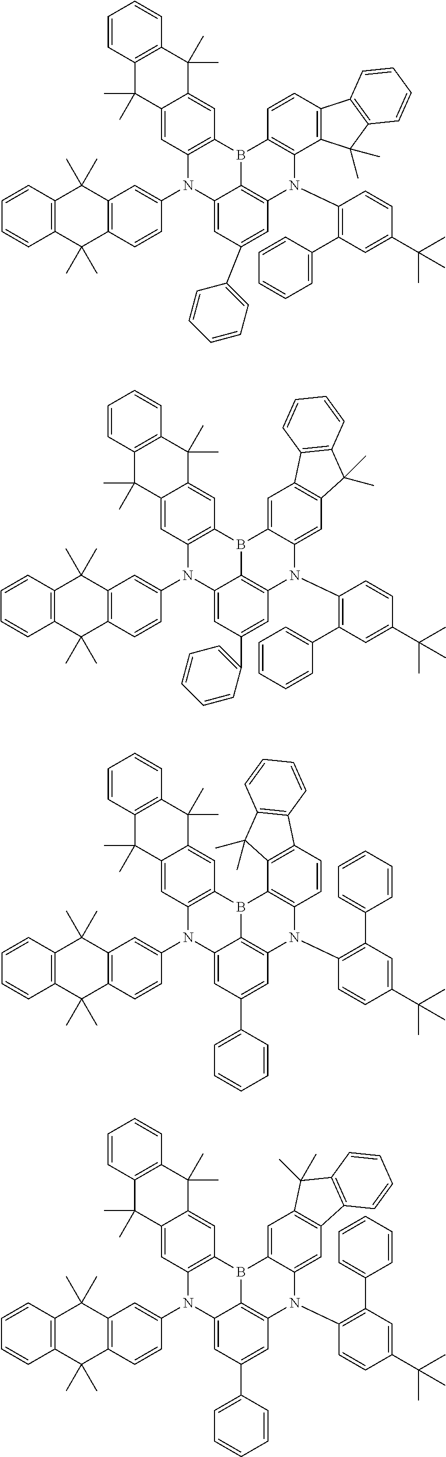

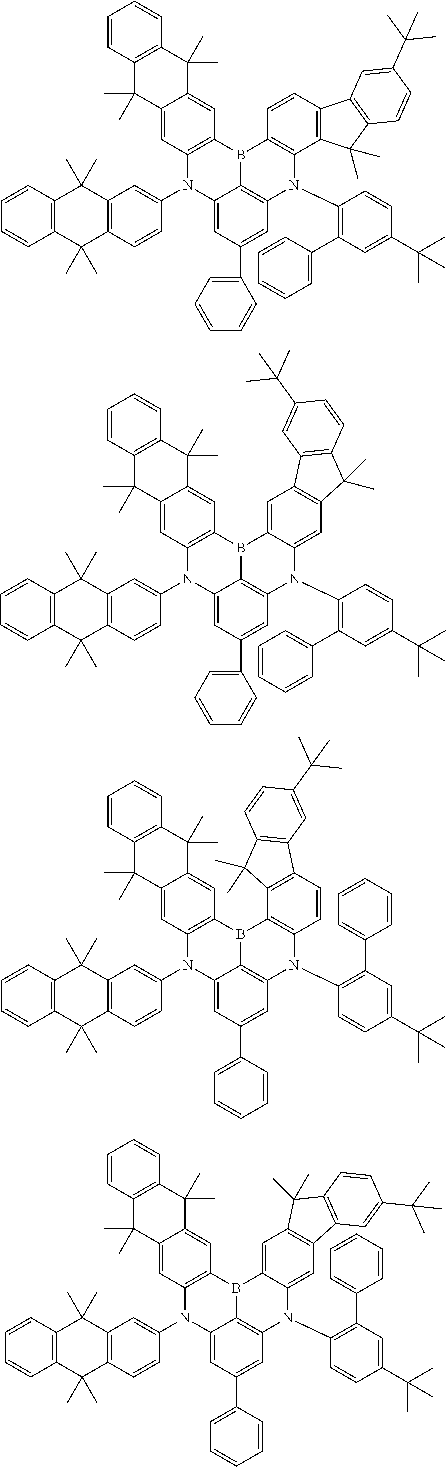

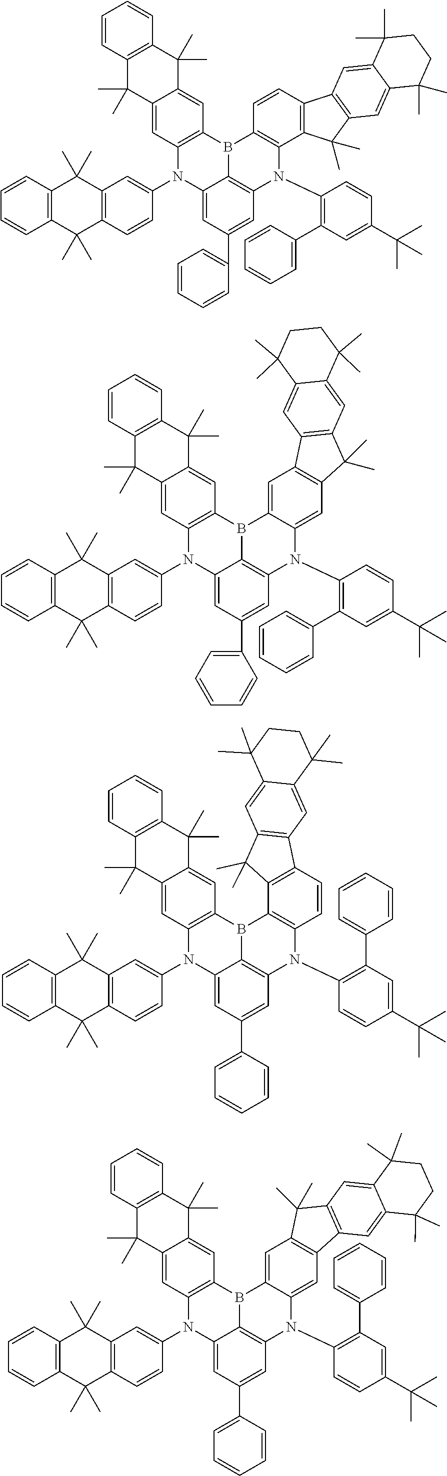

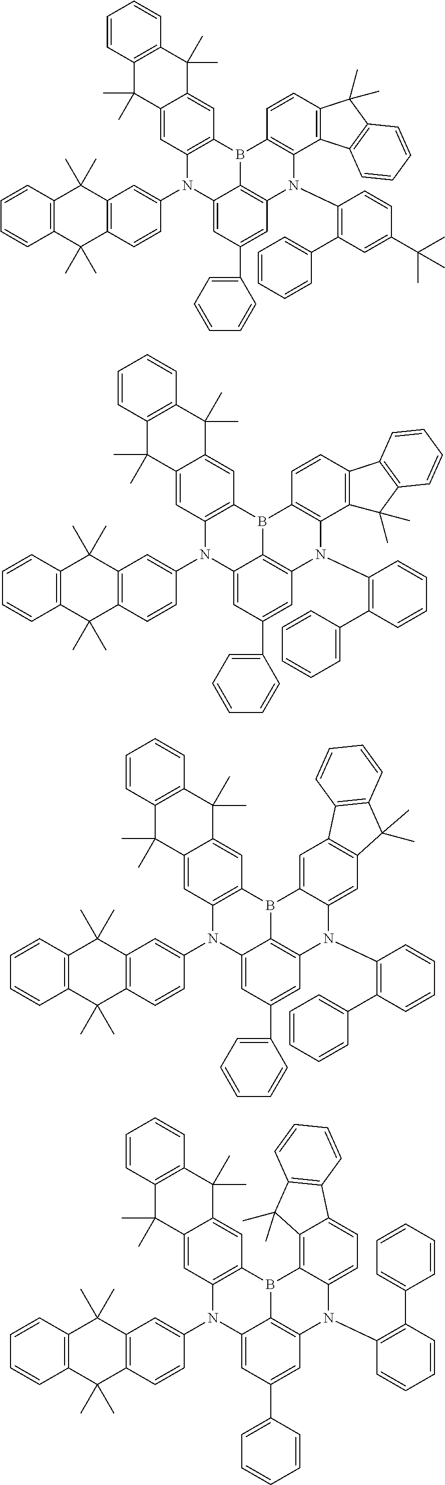

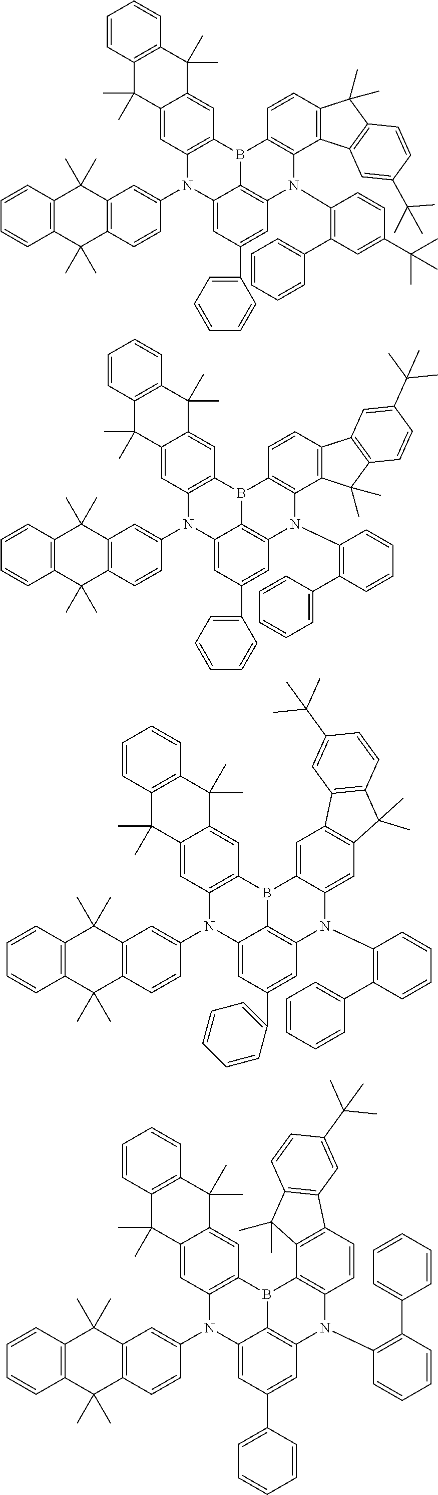

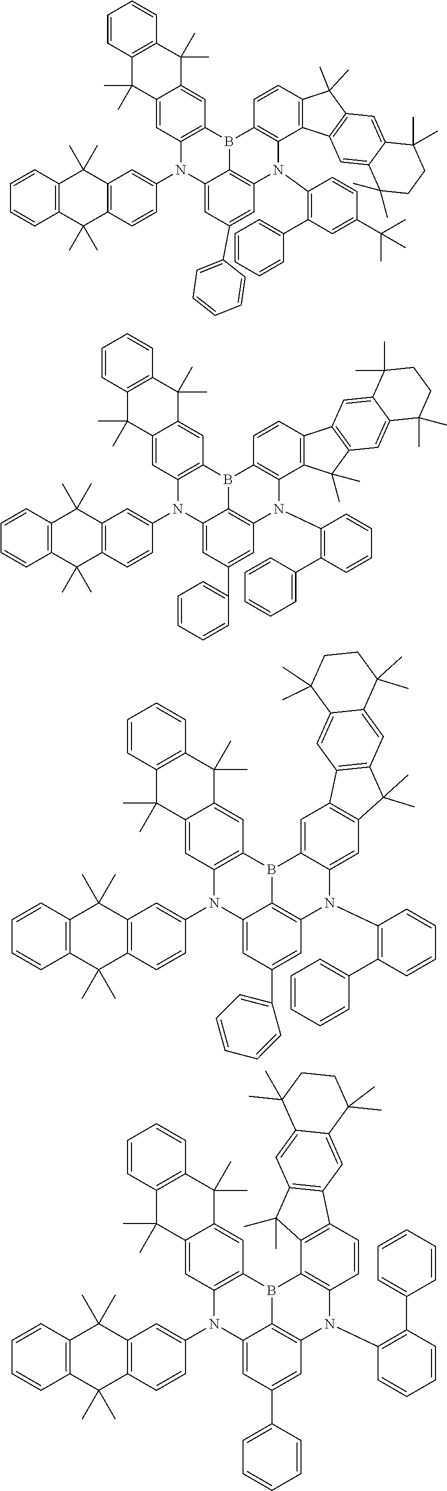

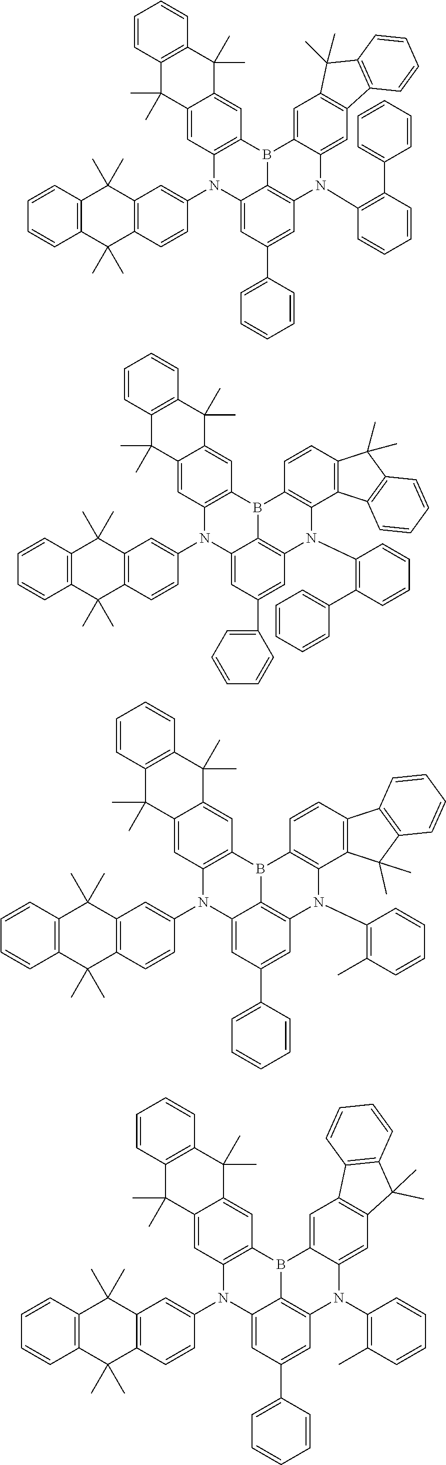

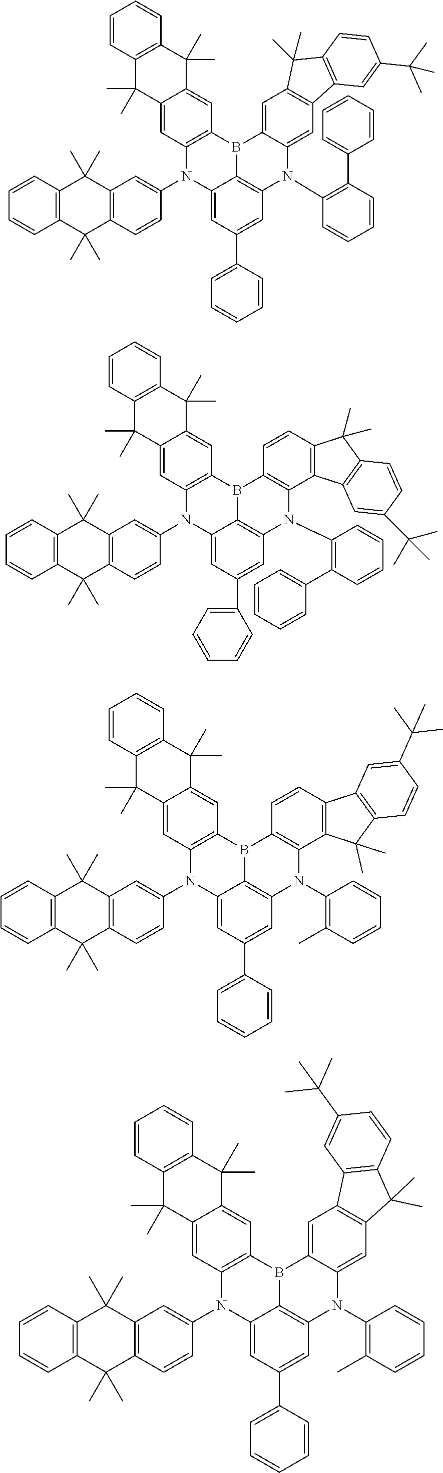

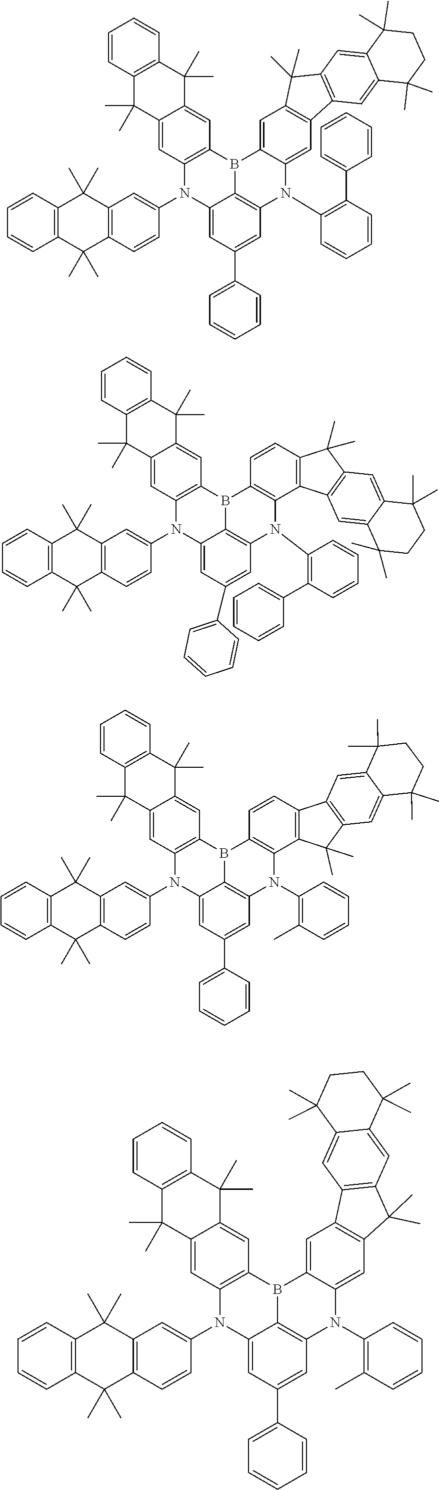

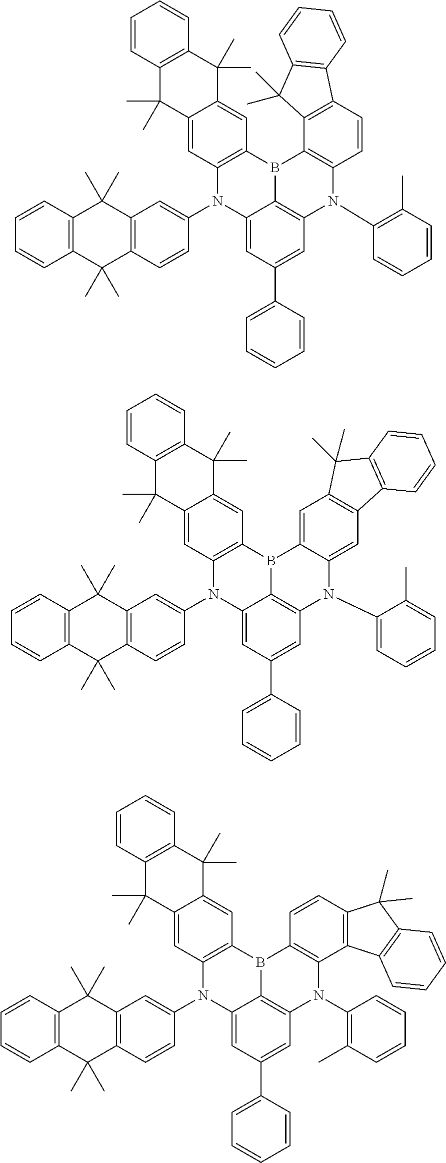 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccccc2-1 ; Cc1ccccc1N1c2cc3c(cc2B2c4cc5c(cc4N(c4ccc6c(c4)C(C)(C)c4ccccc4C6(C)C)c4cc(-c6ccccc6)cc1c42)C(C)(C)c1ccccc1C5(C)C)C(C)(C)c1ccccc1-3 ; Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(c21)-c1ccccc1C3(C)C]

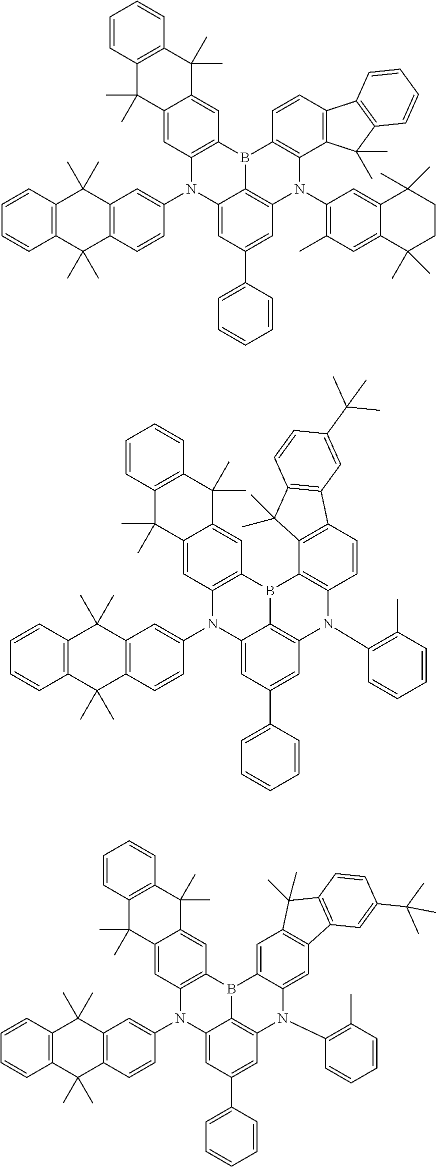 [SMILES: Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1ccccc1-4)C(C)(C)CCC2(C)C ; Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccc(C(C)(C)C)cc2-1 ; Cc1ccccc1N1c2cc3c(cc2B2c4cc5c(cc4N(c4ccc6c(c4)C(C)(C)c4ccccc4C6(C)C)c4cc(-c6ccccc6)cc1c42)C(C)(C)c1ccccc1C5(C)C)C(C)(C)c1ccc(C(C)(C)C)cc1-3]

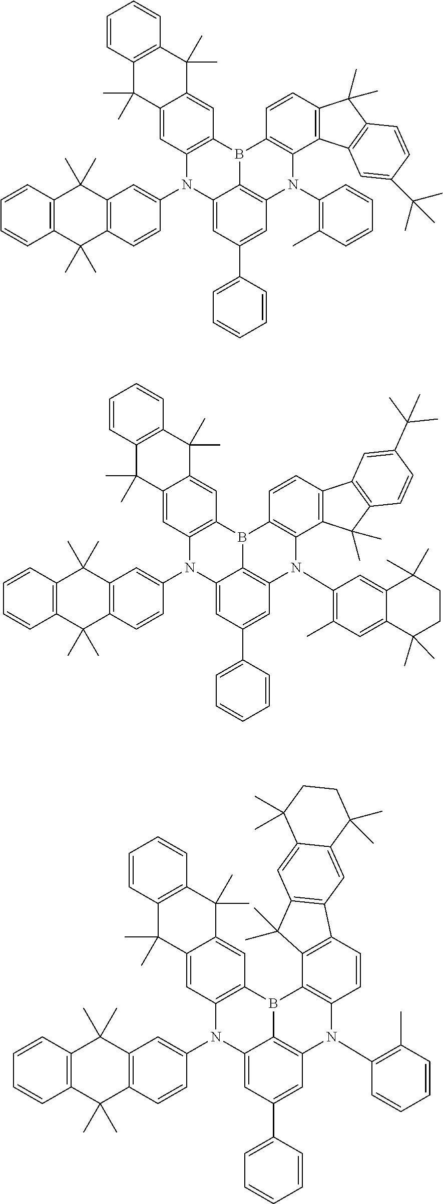 [SMILES: Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2ccc3c(c21)-c1cc(C(C)(C)C)ccc1C3(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1ccc(C(C)(C)C)cc1-4)C(C)(C)CCC2(C)C ; Cc1ccccc1N1c2cc(-c3ccccc3)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2cc3c(cc2-1)C(C)(C)CCC3(C)C]

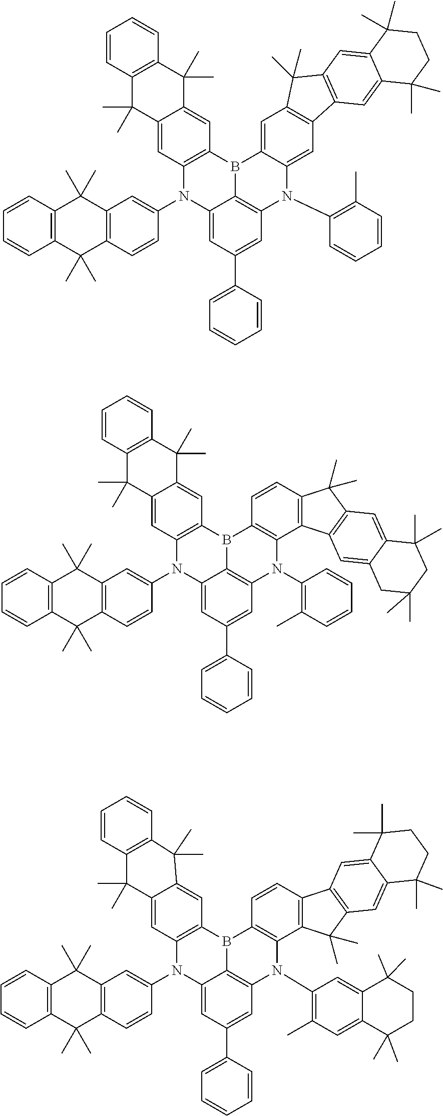

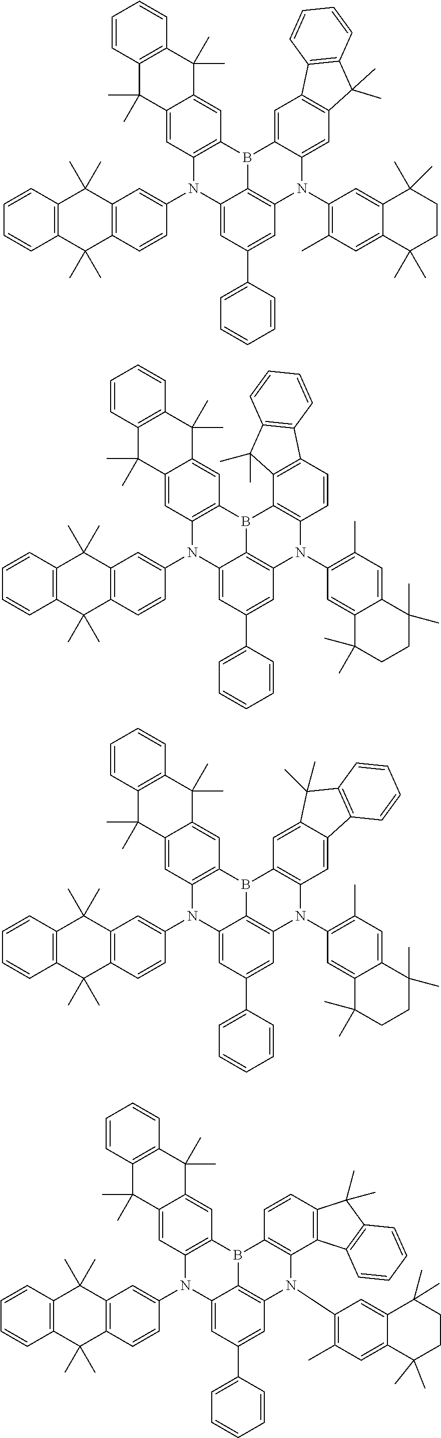

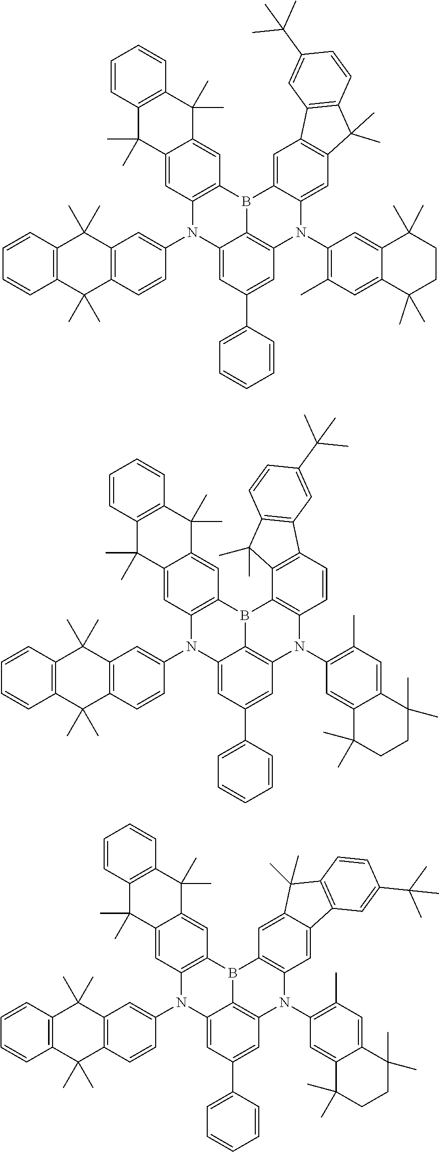 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)-c1cc(C(C)(C)C)ccc1C4(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3C(C)(C)c3ccc(C(C)(C)C)cc3-1)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)C(C)(C)c1ccc(C(C)(C)C)cc1-4)C(C)(C)CCC2(C)C]

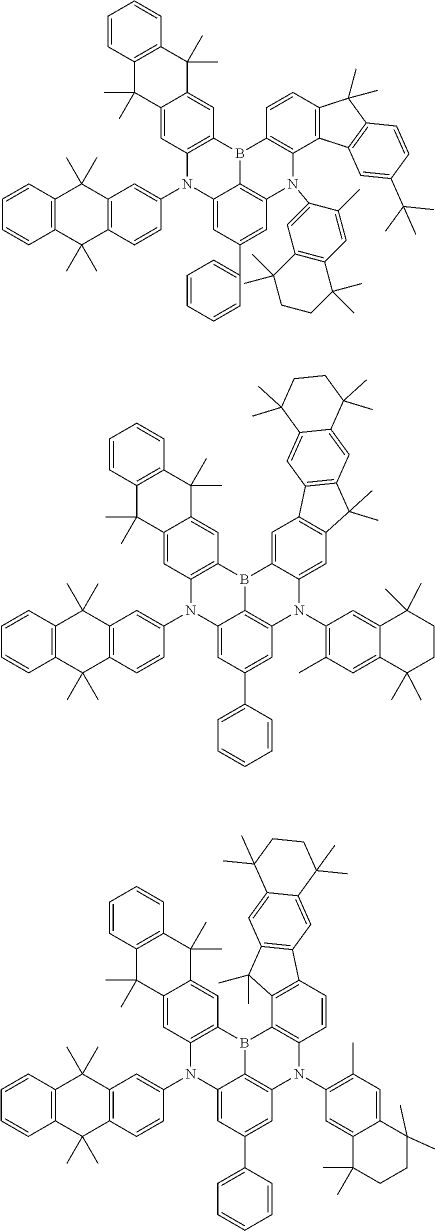 [SMILES: Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)-c1cc(C(C)(C)C)ccc1C4(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)-c1cc3c(cc1C4(C)C)C(C)(C)CCC3(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3c1ccc1c3C(C)(C)c3cc4c(cc3-1)C(C)(C)CCC4(C)C)C(C)(C)CCC2(C)C]

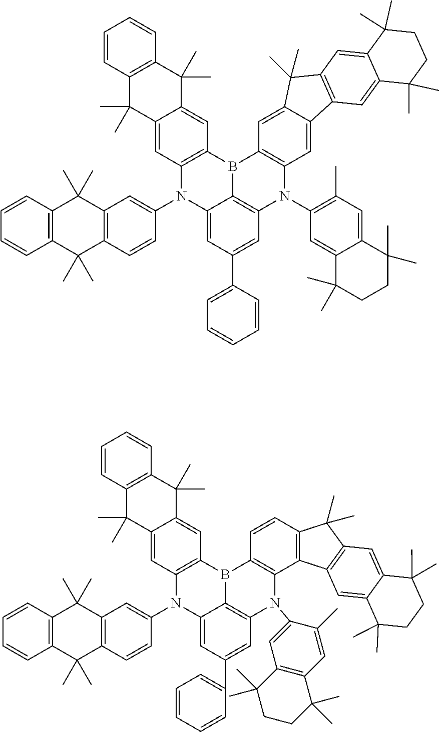 [SMILES: Cc1cc2c(cc1N1c3cc4c(cc3B3c5cc6c(cc5N(c5ccc7c(c5)C(C)(C)c5ccccc5C7(C)C)c5cc(-c7ccccc7)cc1c53)C(C)(C)c1ccccc1C6(C)C)C(C)(C)c1cc3c(cc1-4)C(C)(C)CCC3(C)C)C(C)(C)CCC2(C)C ; Cc1cc2c(cc1N1c3cc(-c4ccccc4)cc4c3B(c3cc5c(cc3N4c3ccc4c(c3)C(C)(C)c3ccccc3C4(C)C)C(C)(C)c3ccccc3C5(C)C)c3ccc4c(c31)-c1cc3c(cc1C4(C)C)C(C)(C)CCC3(C)C)C(C)(C)CCC2(C)C]

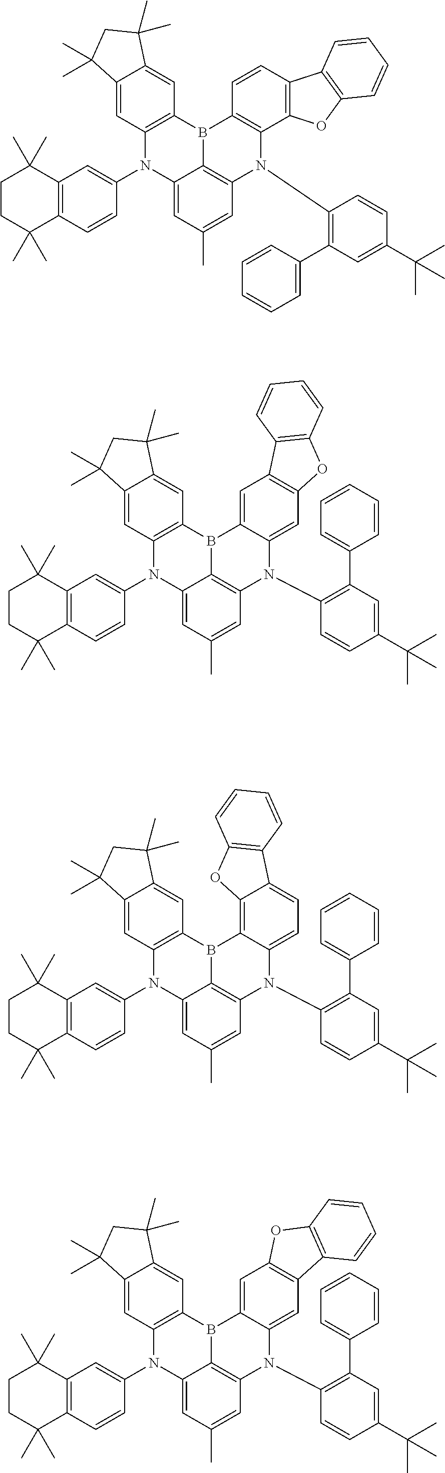 [SMILES: Cc1cc2c3c(c1)N(c1ccc(C(C)(C)C)cc1-c1ccccc1)c1c(ccc4c1oc1ccccc14)B3c1cc3c(cc1N2c1ccc2c(c1)C(C)(C)CCC2(C)C)C(C)(C)CC3(C)C ; Cc1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)CCC2(C)C)C(C)(C)CC3(C)C ; Cc1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)CCC2(C)C)C(C)(C)CC3(C)C ; Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CC3(C)C)oc1ccccc14]

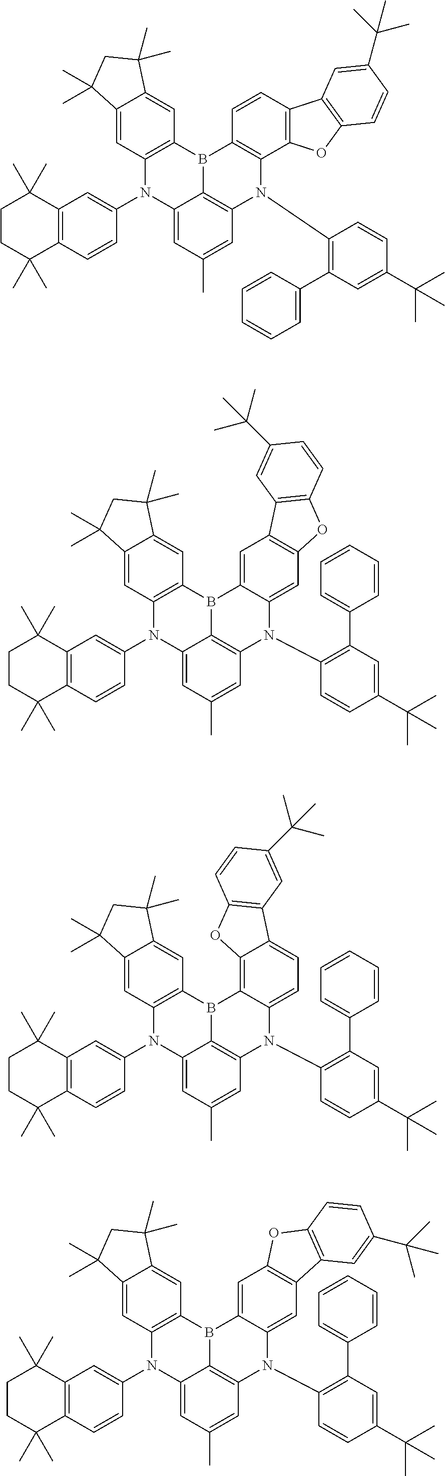

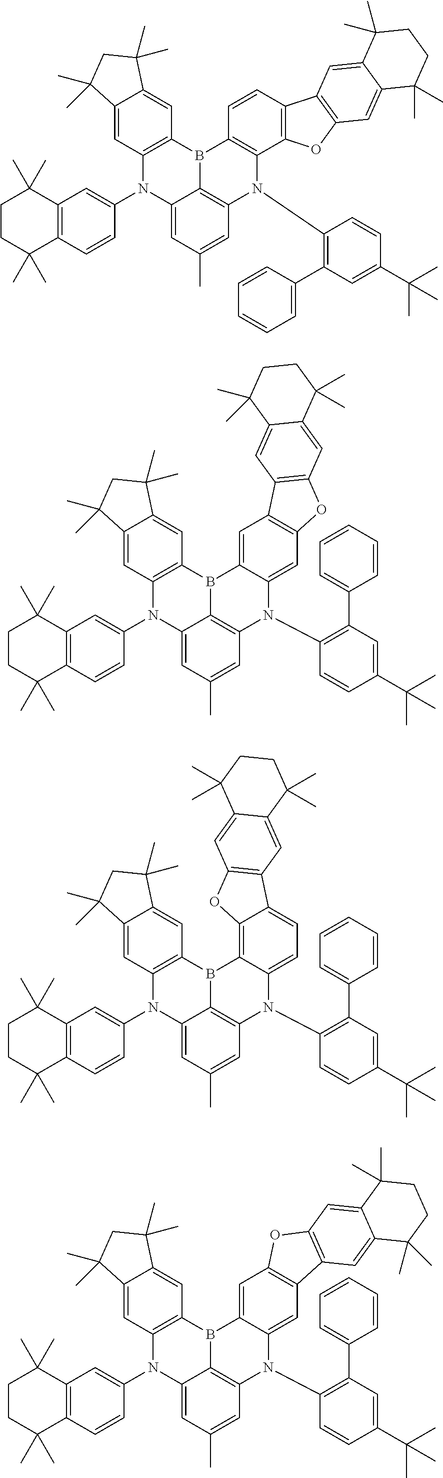

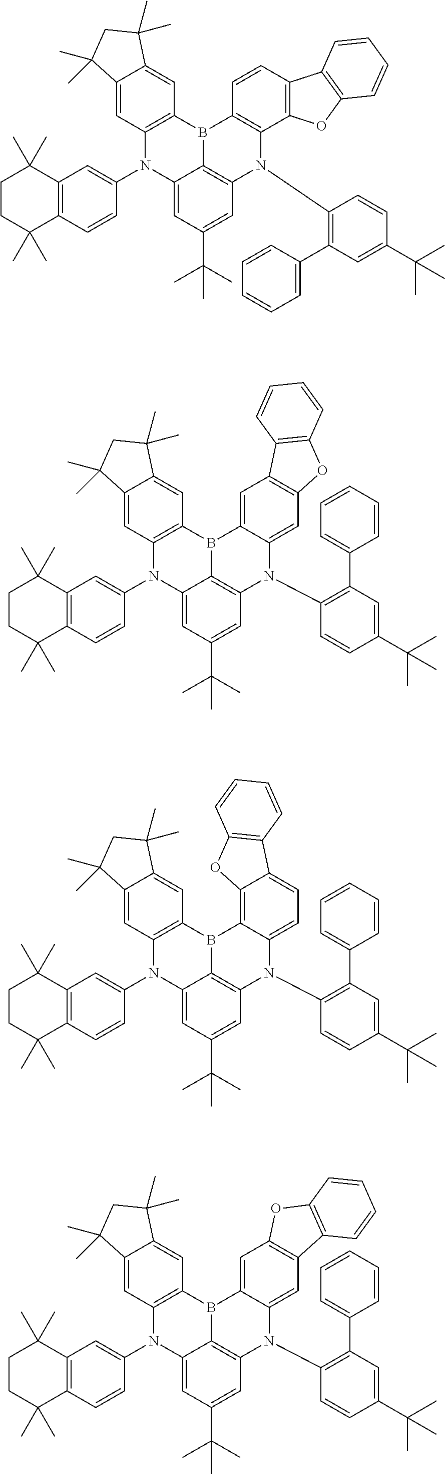

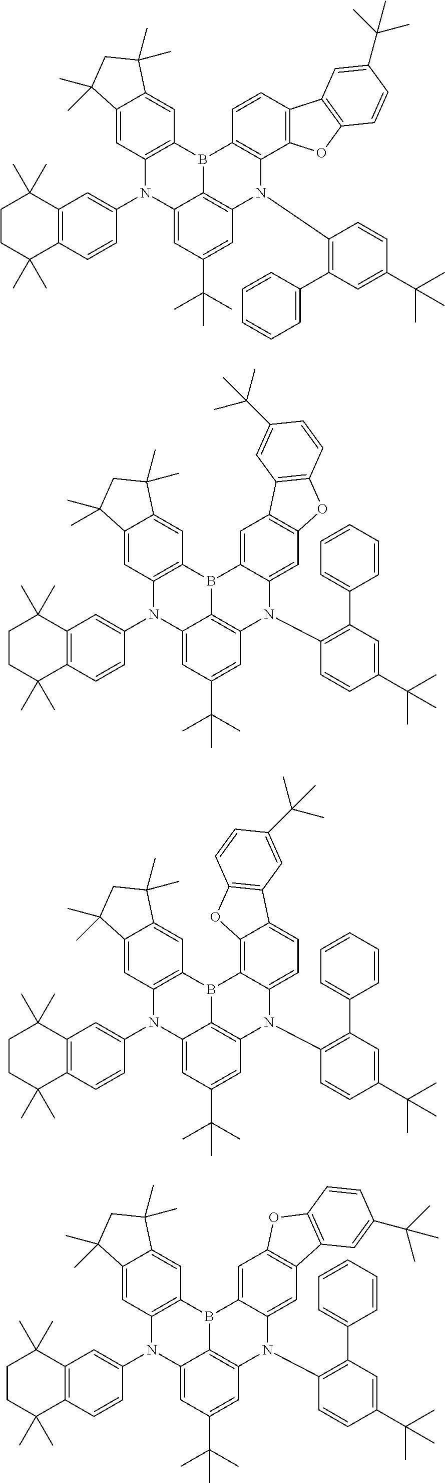

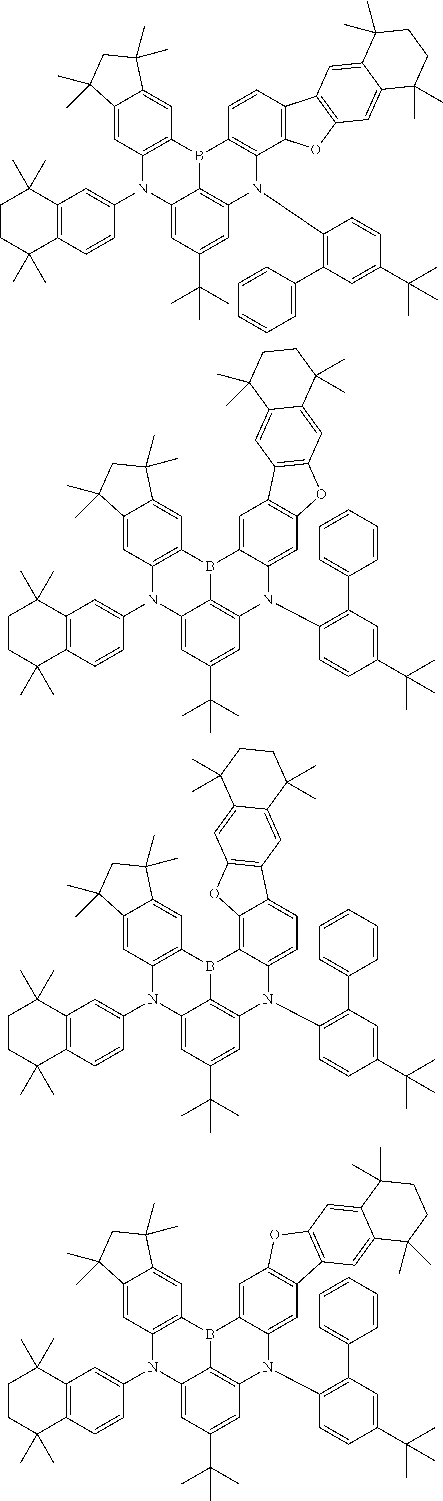

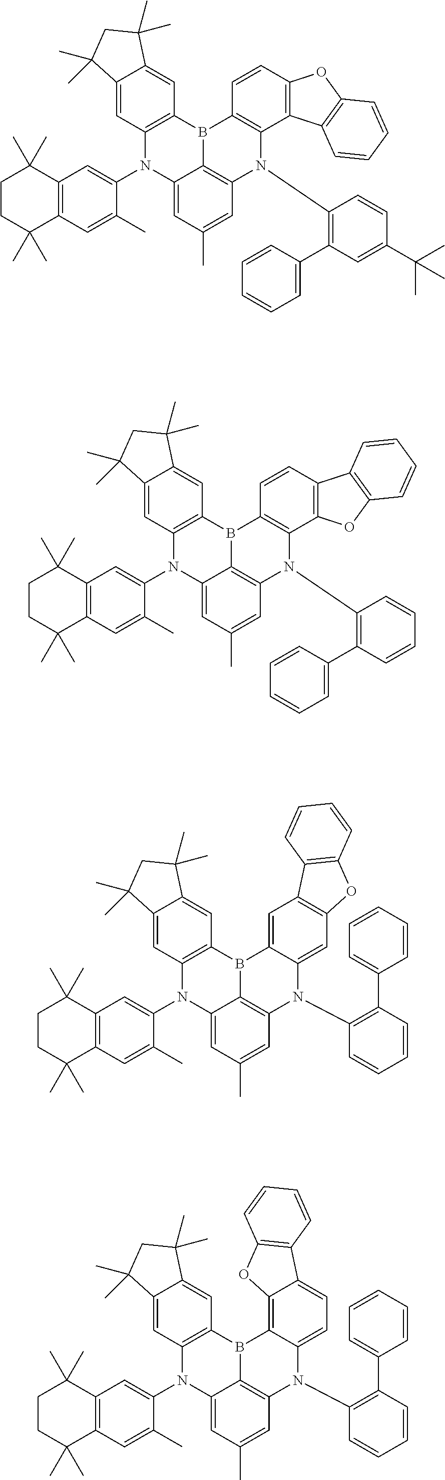 [SMILES: Cc1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1c(ccc4c1oc1ccccc14)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1cc4oc5ccccc5c4cc1B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1ccc4c(oc5ccccc54)c1B3c1cc3c(cc1N2c1cc2c(cc1C)C(C)(C)CCC2(C)C)C(C)(C)CC3(C)C]

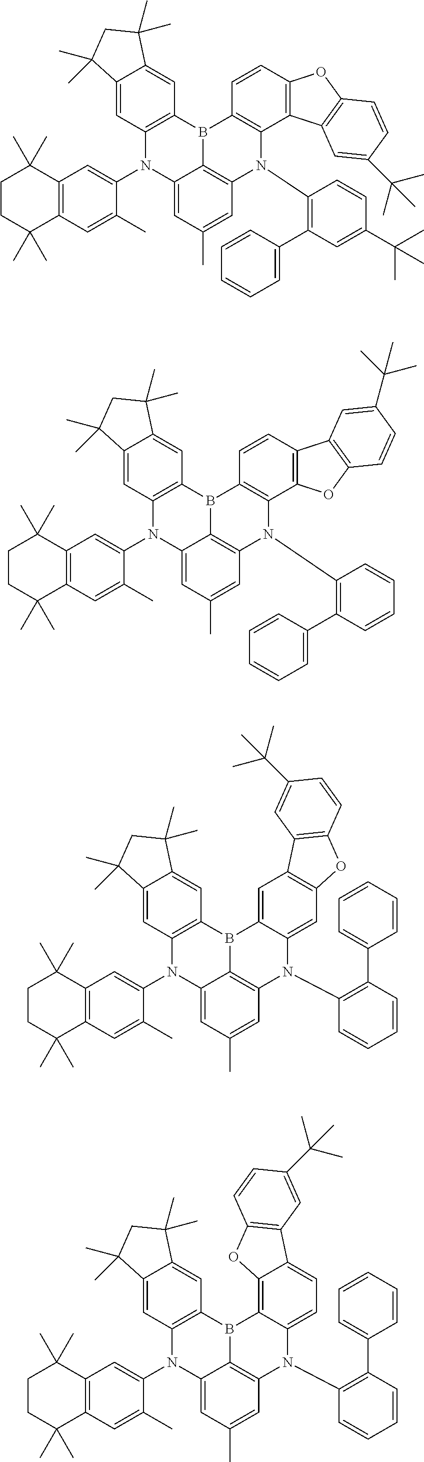

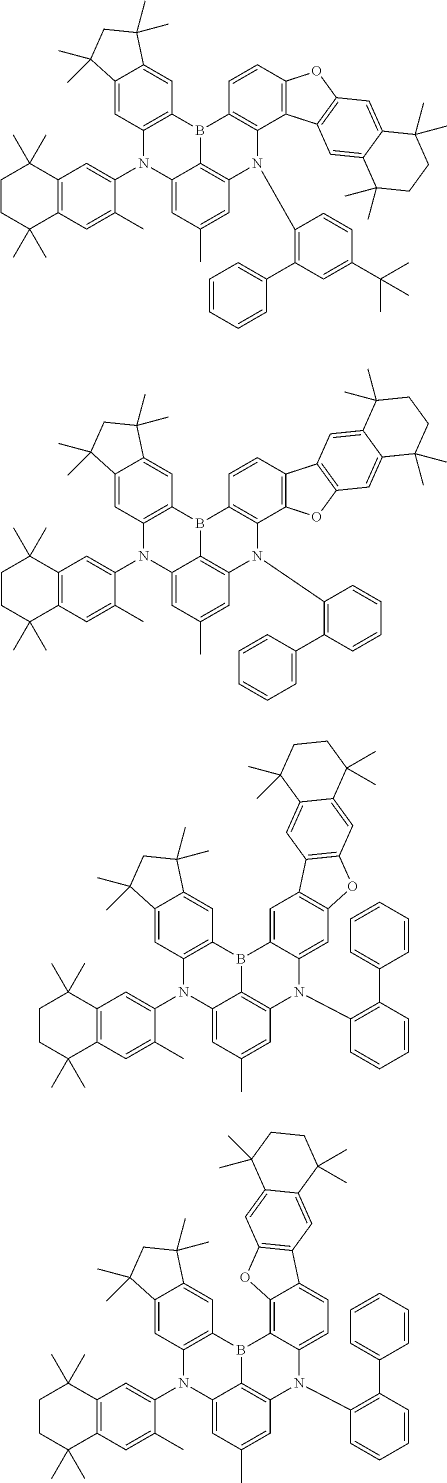

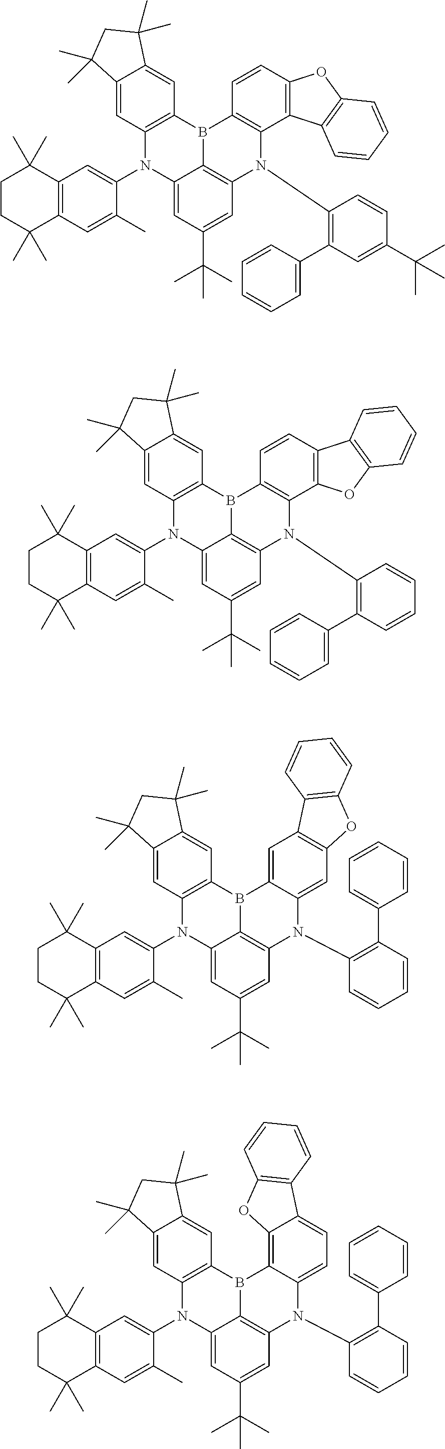 [SMILES: Cc1cc2c(cc1N1c3cc4c(cc3B3c5ccc6oc7ccccc7c6c5N(c5ccc(C(C)(C)C)cc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)oc1ccccc16)C(C)(C)CC4(C)C)C(C)(C)CCC2(C)C ; Cc1cc2c(cc1N1c3cc4c(cc3B3c5c1cc(C(C)(C)C)cc5N(c1ccccc1-c1ccccc1)c1ccc5c(oc6ccccc65)c13)C(C)(C)CC4(C)C)C(C)(C)CCC2(C)C]

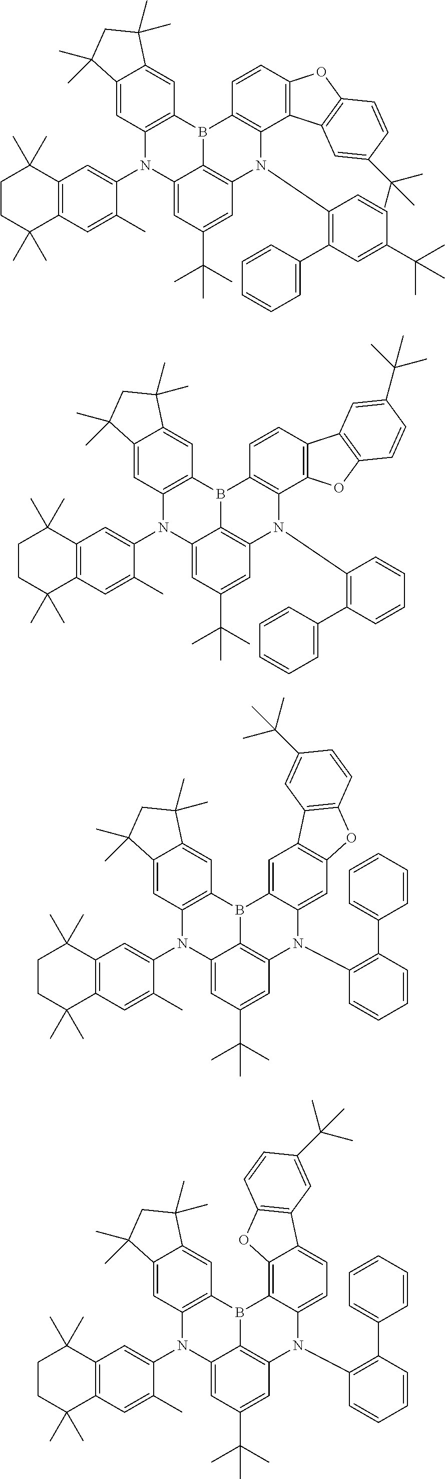

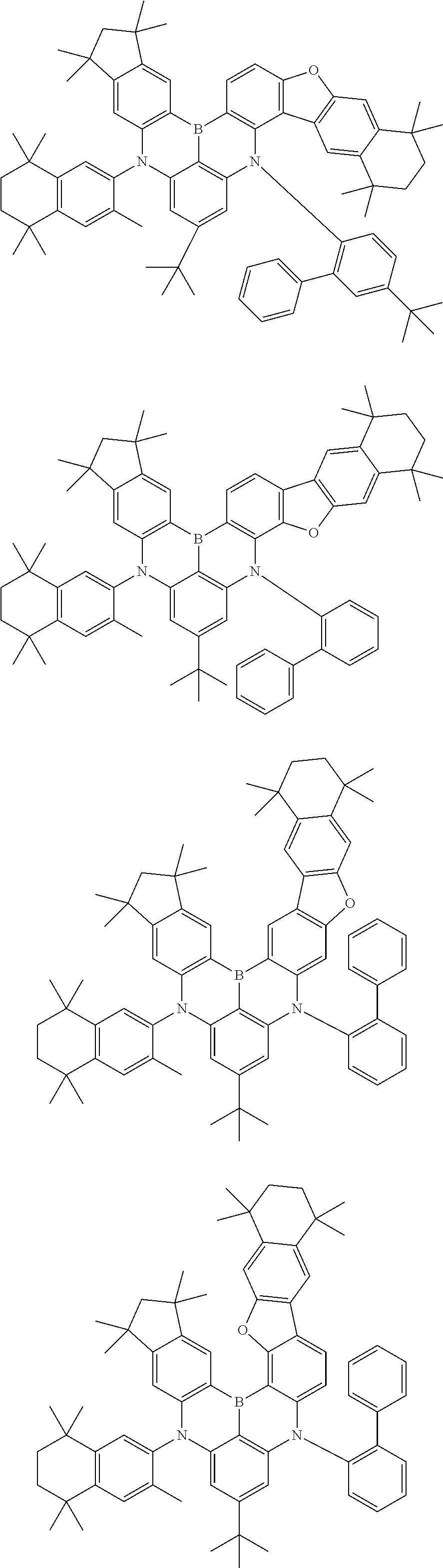

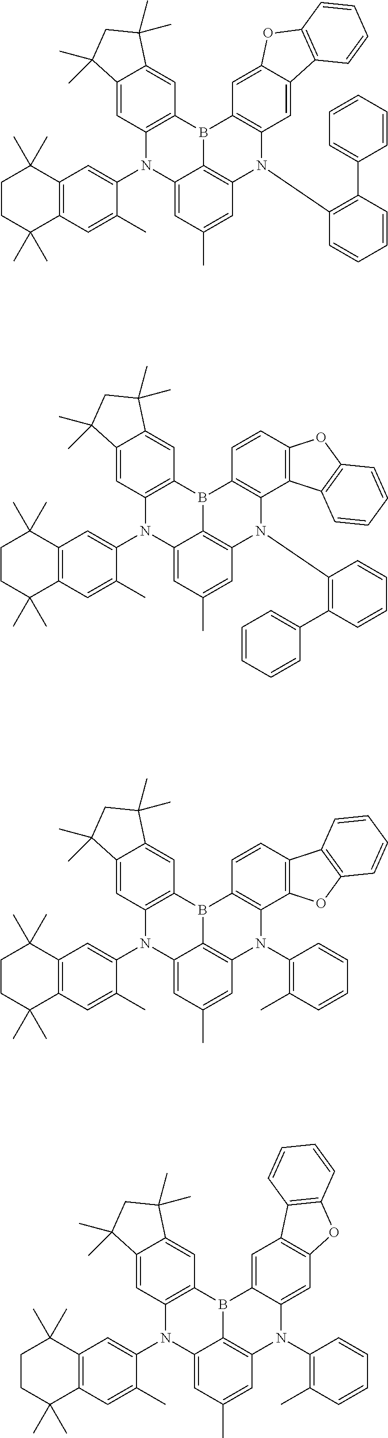 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)oc1ccccc14 ; Cc1cc2c3c(c1)N(c1ccccc1-c1ccccc1)c1c(ccc4oc5ccccc5c14)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1oc1ccccc14)B3c1cc3c(cc1N2c1cc2c(cc1C)C(C)(C)CCC2(C)C)C(C)(C)CC3(C)C ; Cc1cc2c3c(c1)N(c1ccccc1C)c1cc4oc5ccccc5c4cc1B3c1cc3c(cc1N2c1cc2c(cc1C)C(C)(C)CCC2(C)C)C(C)(C)CC3(C)C]

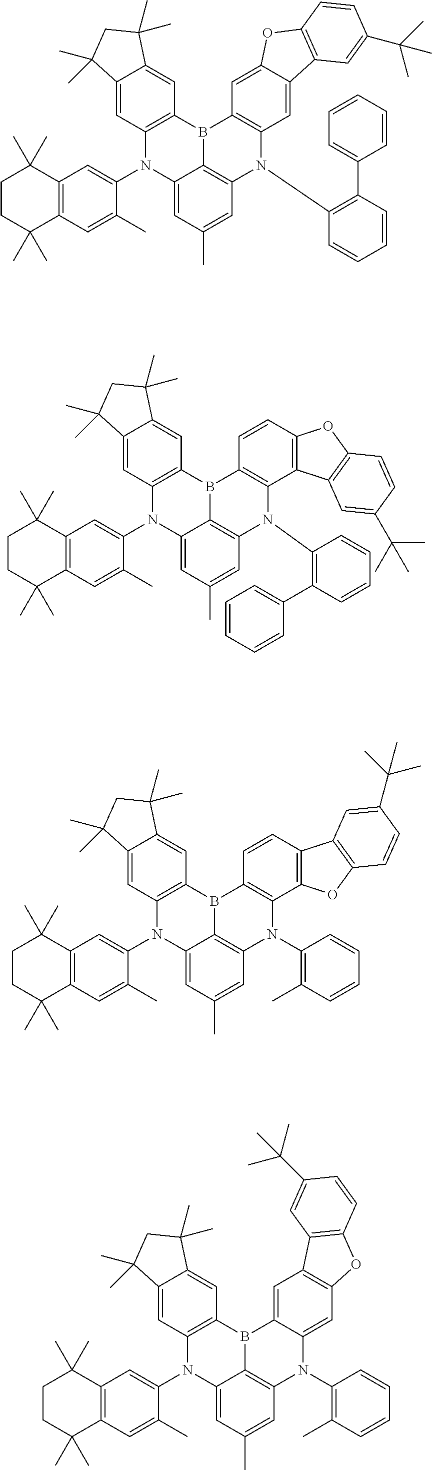 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)oc1ccc(C(C)(C)C)cc14 ; Cc1cc2c3c(c1)N(c1ccccc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1oc1ccc(C(C)(C)C)cc14)B3c1cc3c(cc1N2c1cc2c(cc1C)C(C)(C)CCC2(C)C)C(C)(C)CC3(C)C ; Cc1cc2c3c(c1)N(c1ccccc1C)c1cc4oc5ccc(C(C)(C)C)cc5c4cc1B3c1cc3c(cc1N2c1cc2c(cc1C)C(C)(C)CCC2(C)C)C(C)(C)CC3(C)C]

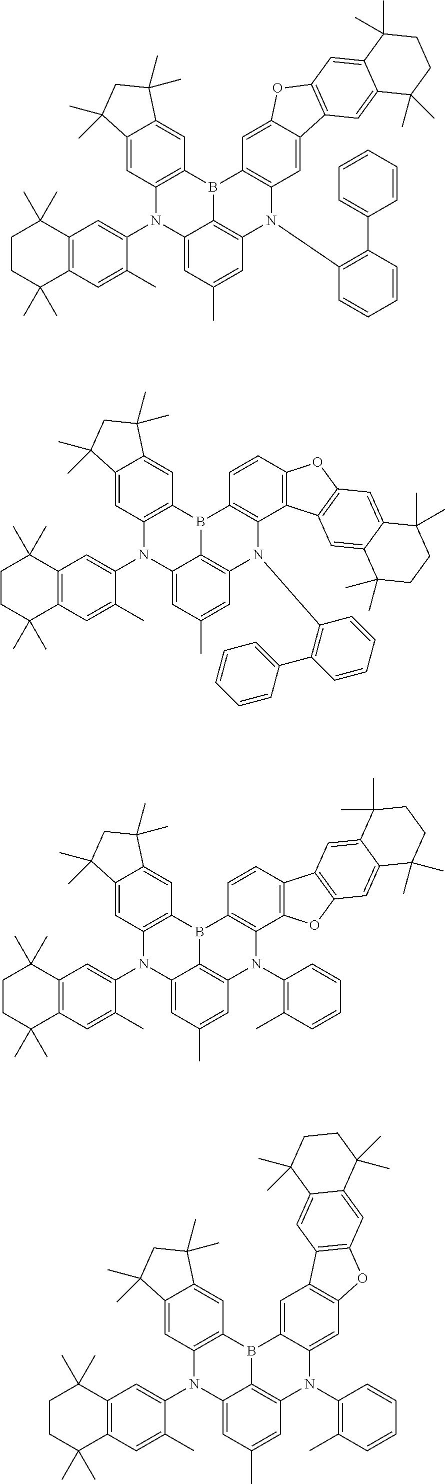

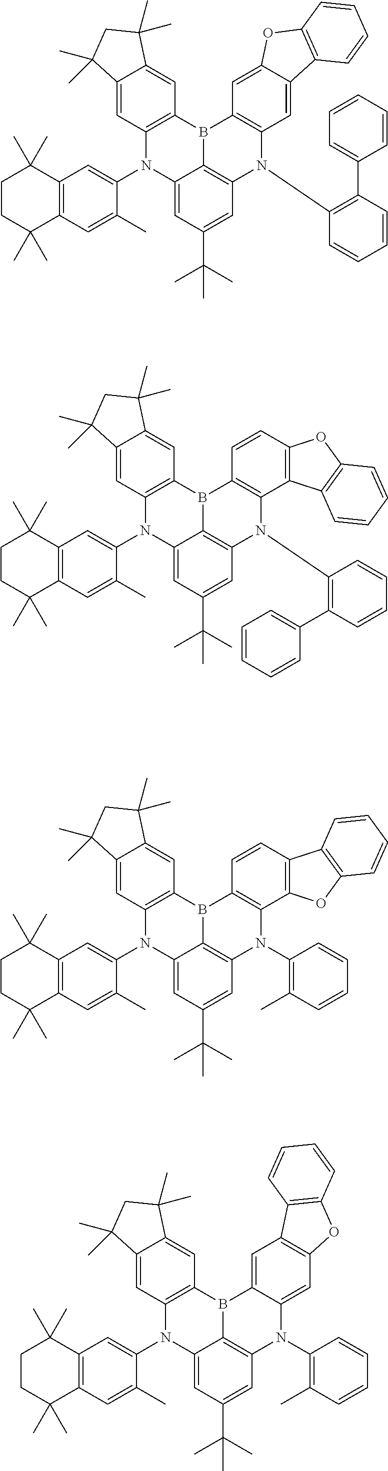 [SMILES: Cc1cc2c(cc1N1c3cc4c(cc3B3c5cc6oc7ccccc7c6cc5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5C)c5cc(C(C)(C)C)cc1c53)C(C)(C)CC4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(C(C)(C)C)cc1c32)C(C)(C)CC4(C)C]

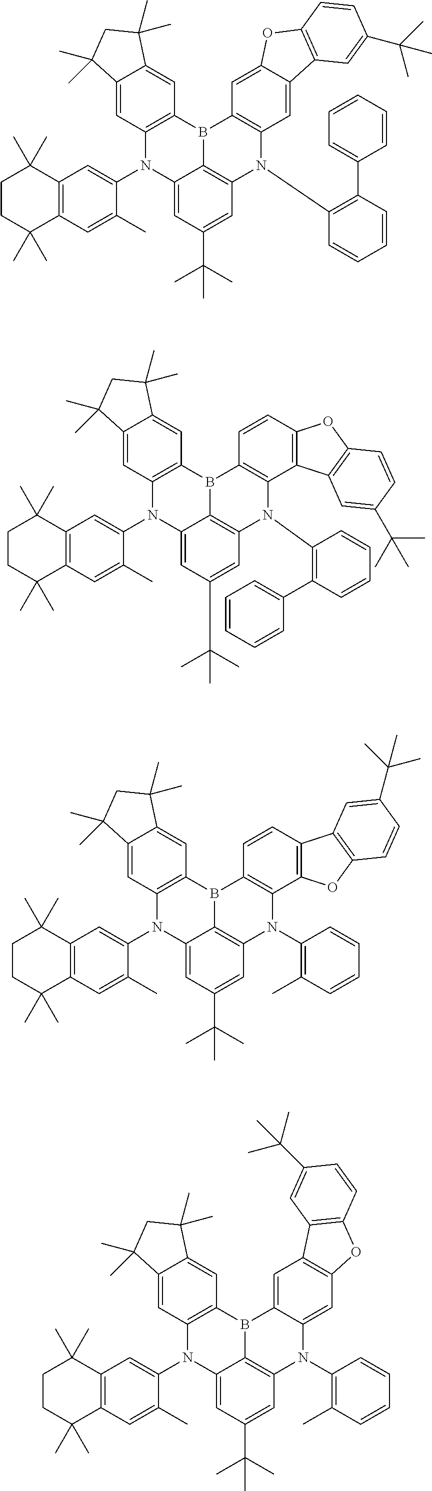 [SMILES: Cc1cc2c(cc1N1c3cc4c(cc3B3c5cc6oc7ccc(C(C)(C)C)cc7c6cc5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6oc7ccc(C(C)(C)C)cc7c6c5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5ccccc5C)c5cc(C(C)(C)C)cc1c53)C(C)(C)CC4(C)C)C(C)(C)CCC2(C)C ; Cc1ccccc1N1c2cc3oc4ccc(C(C)(C)C)cc4c3cc2B2c3cc4c(cc3N(c3cc5c(cc3C)C(C)(C)CCC5(C)C)c3cc(C(C)(C)C)cc1c32)C(C)(C)CC4(C)C]

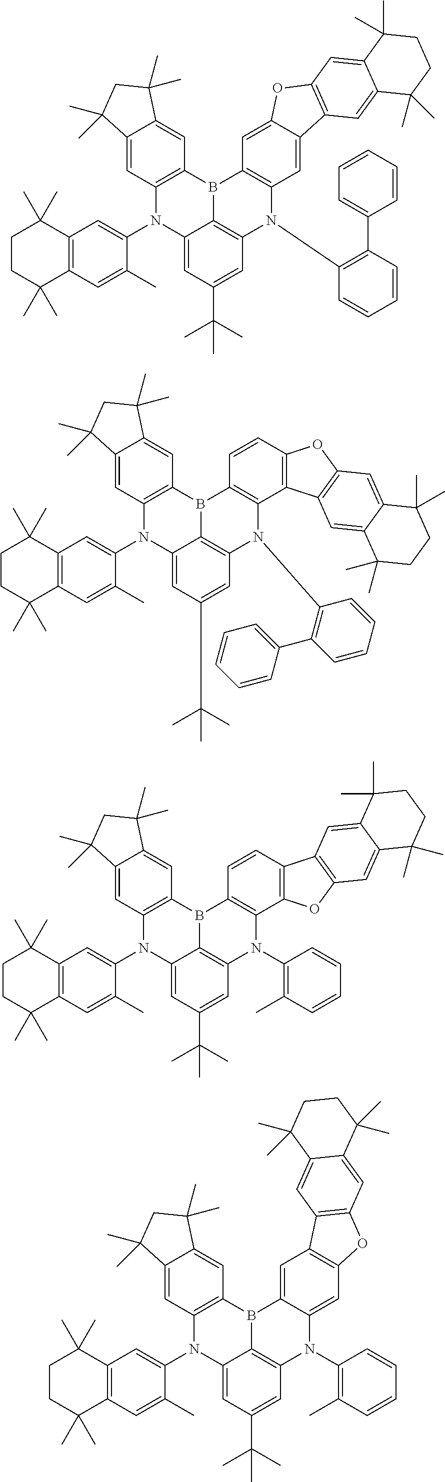

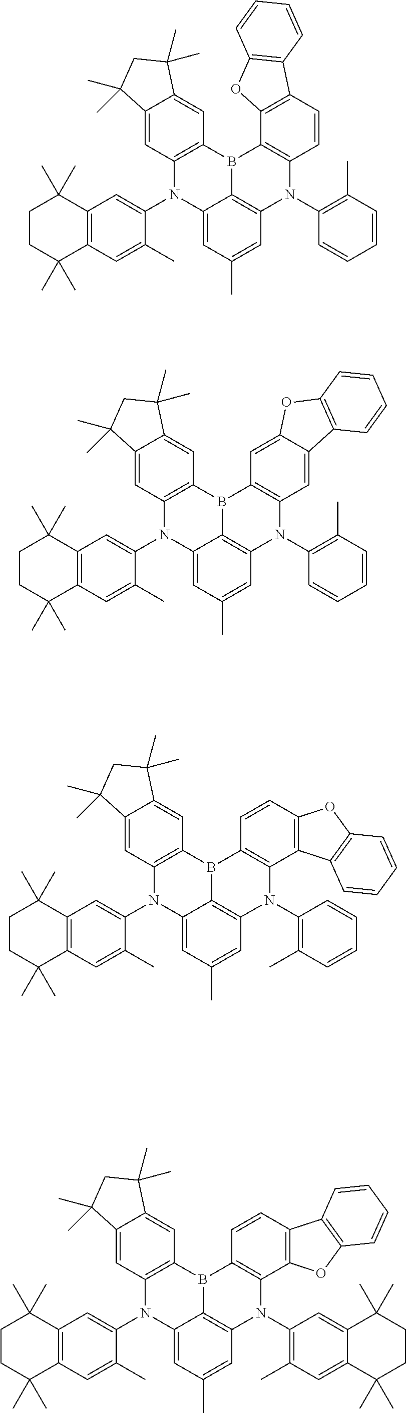 [SMILES: Cc1cc2c3c(c1)N(c1ccccc1C)c1ccc4c(oc5ccccc54)c1B3c1cc3c(cc1N2c1cc2c(cc1C)C(C)(C)CCC2(C)C)C(C)(C)CC3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1ccccc14 ; Cc1cc2c3c(c1)N(c1ccccc1C)c1c(ccc4oc5ccccc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)CC3(C)C]

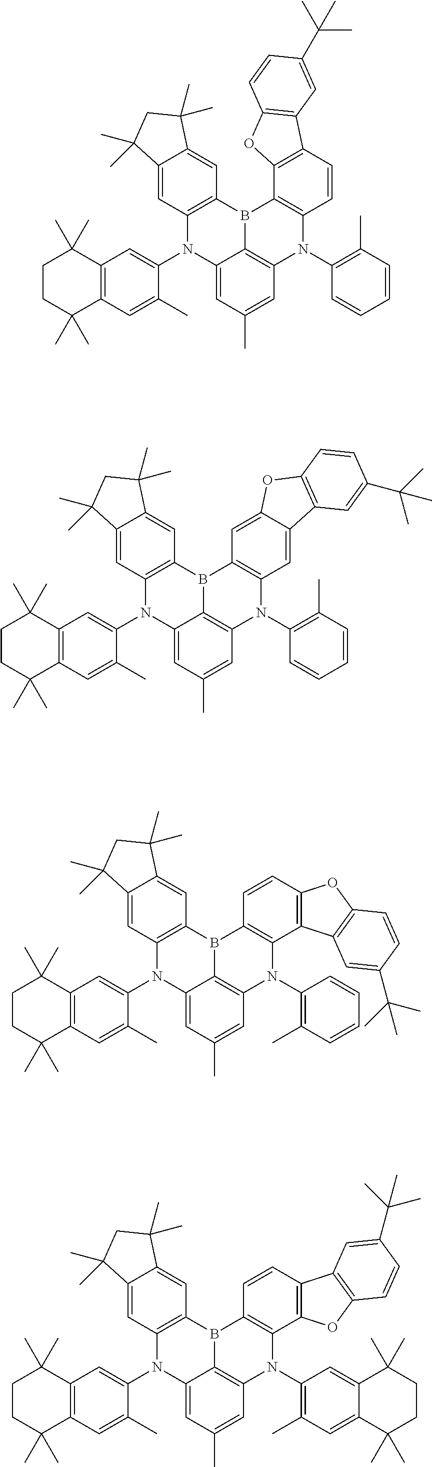 [SMILES: Cc1cc2c3c(c1)N(c1ccccc1C)c1ccc4c(oc5ccc(C(C)(C)C)cc54)c1B3c1cc3c(cc1N2c1cc2c(cc1C)C(C)(C)CCC2(C)C)C(C)(C)CC3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1ccc(C(C)(C)C)cc14 ; Cc1cc2c3c(c1)N(c1ccccc1C)c1c(ccc4oc5ccc(C(C)(C)C)cc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1oc1ccc(C(C)(C)C)cc14)B3c1cc3c(cc1N2c1cc2c(cc1C)C(C)(C)CCC2(C)C)C(C)(C)CC3(C)C]

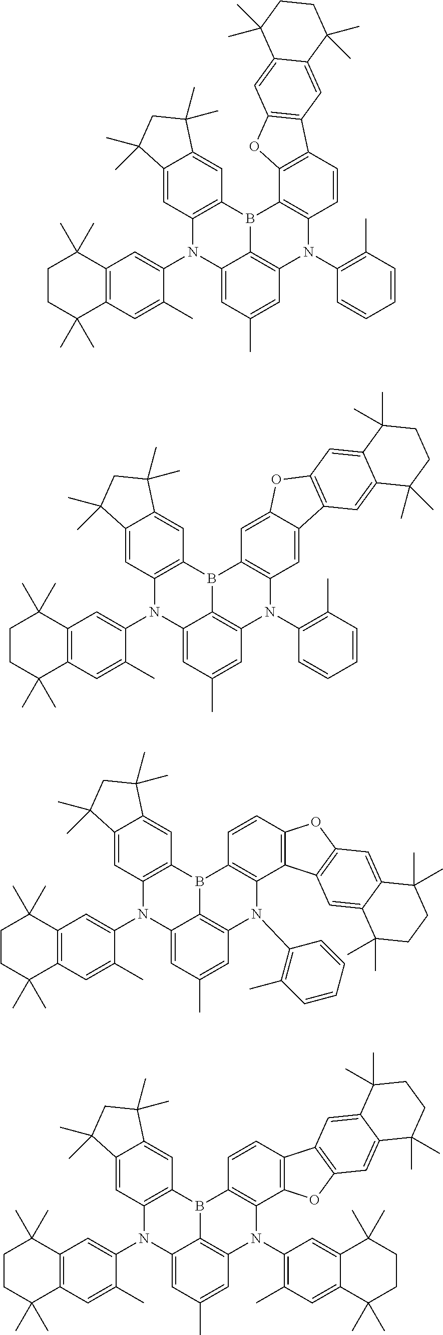

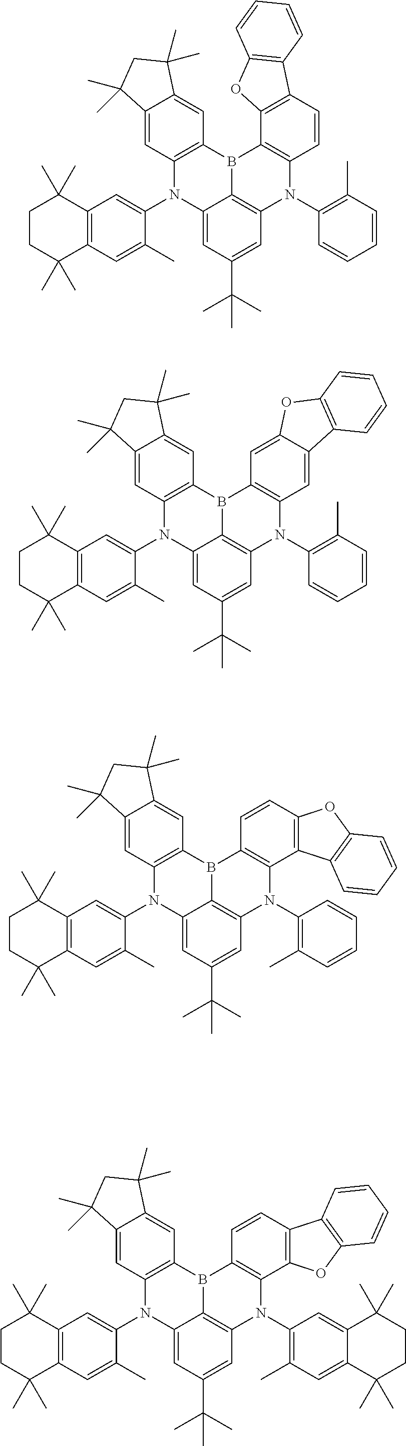 [SMILES: Cc1cc2c(cc1N1c3cc4c(cc3B3c5c1cc(C(C)(C)C)cc5N(c1ccccc1C)c1ccc5c(oc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)oc1ccccc13 ; Cc1cc2c(cc1N1c3cc4c(cc3B3c5ccc6oc7ccccc7c6c5N(c5ccccc5C)c5cc(C(C)(C)C)cc1c53)C(C)(C)CC4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(C(C)(C)C)cc1c53)C(C)(C)CC4(C)C)C(C)(C)CCC2(C)C]

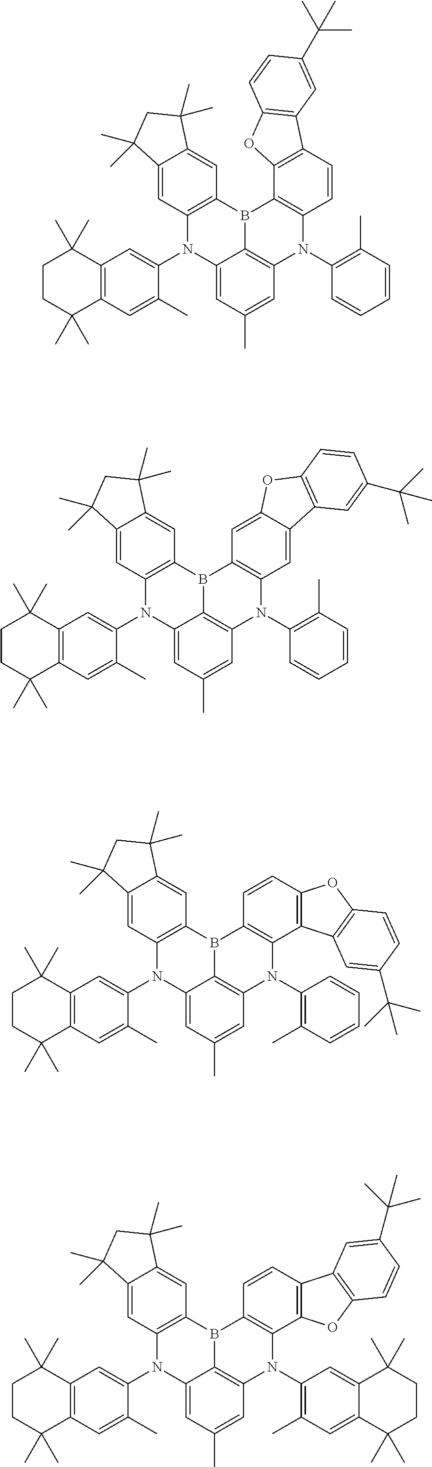 [SMILES: Cc1cc2c3c(c1)N(c1ccccc1C)c1ccc4c(oc5ccc(C(C)(C)C)cc54)c1B3c1cc3c(cc1N2c1cc2c(cc1C)C(C)(C)CCC2(C)C)C(C)(C)CC3(C)C ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)oc1ccc(C(C)(C)C)cc14 ; Cc1cc2c3c(c1)N(c1ccccc1C)c1c(ccc4oc5ccc(C(C)(C)C)cc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1oc1ccc(C(C)(C)C)cc14)B3c1cc3c(cc1N2c1cc2c(cc1C)C(C)(C)CCC2(C)C)C(C)(C)CC3(C)C]

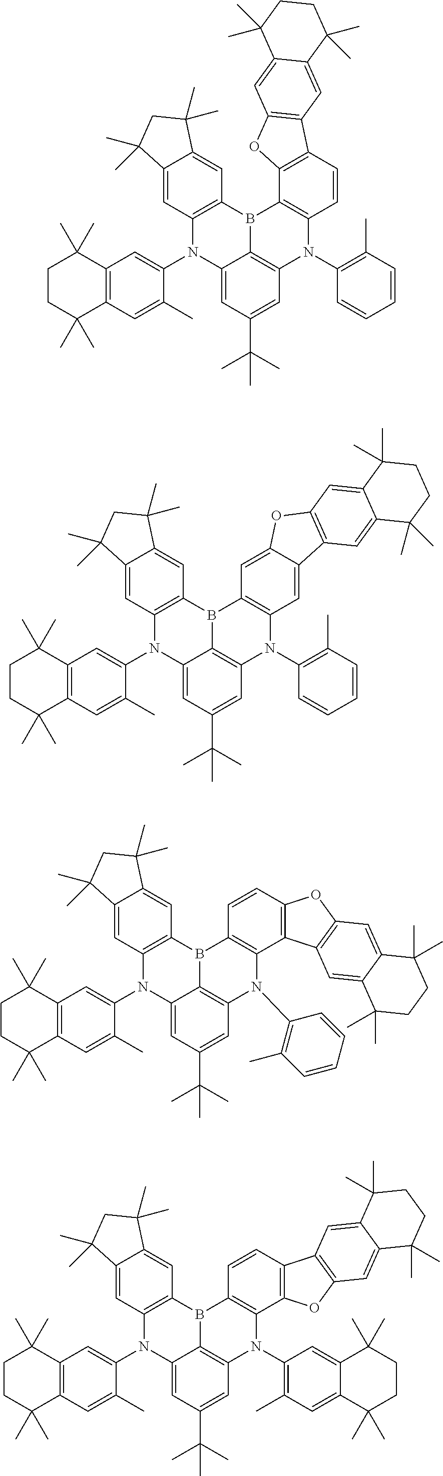

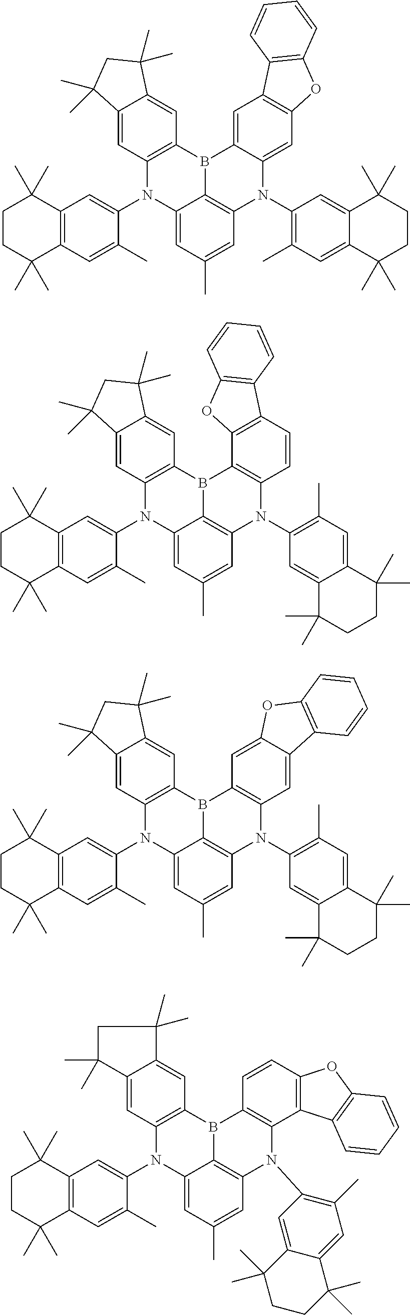

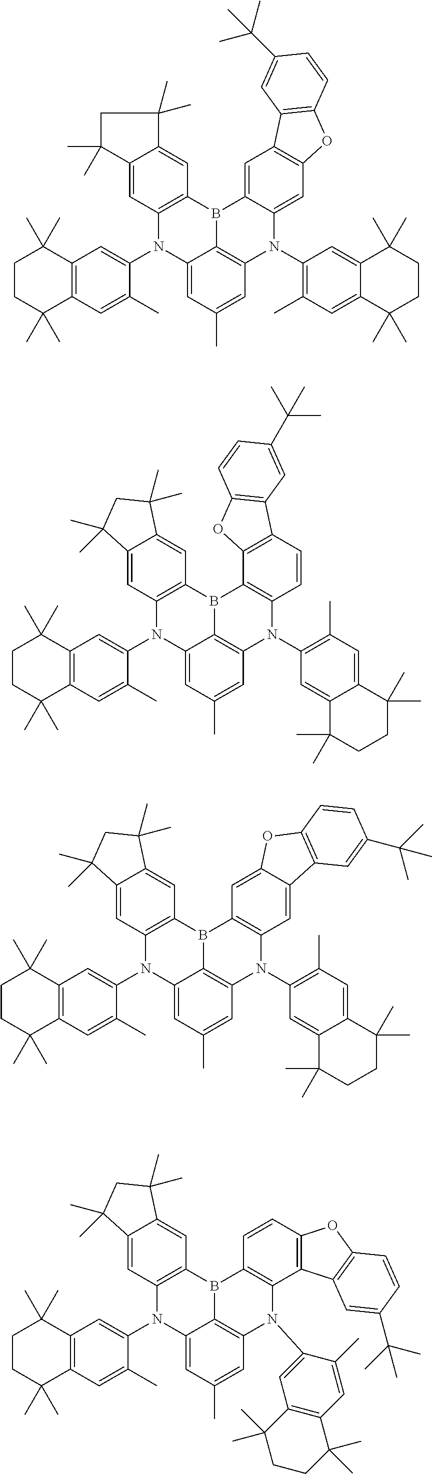

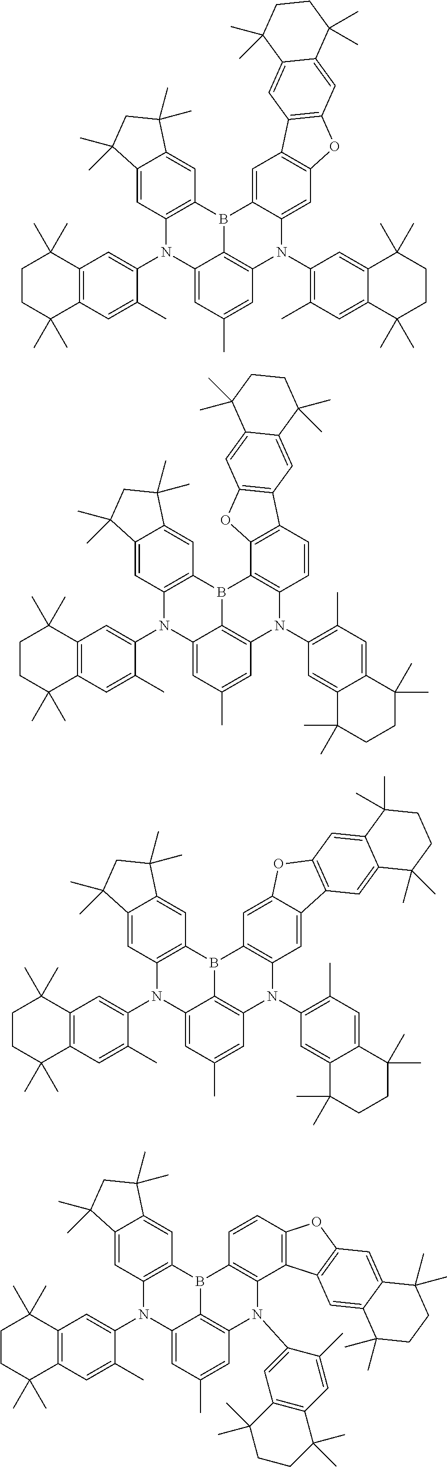

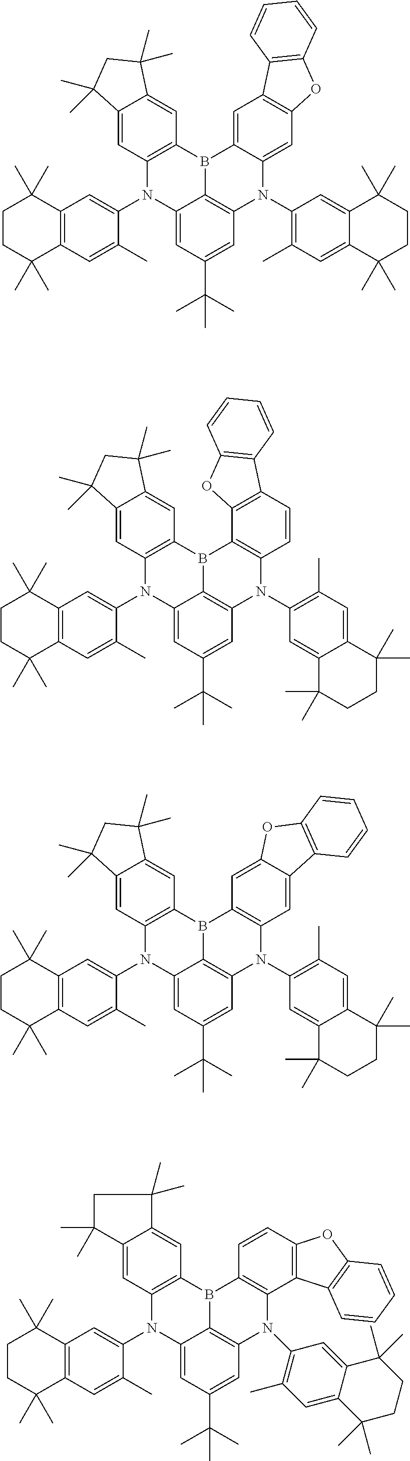

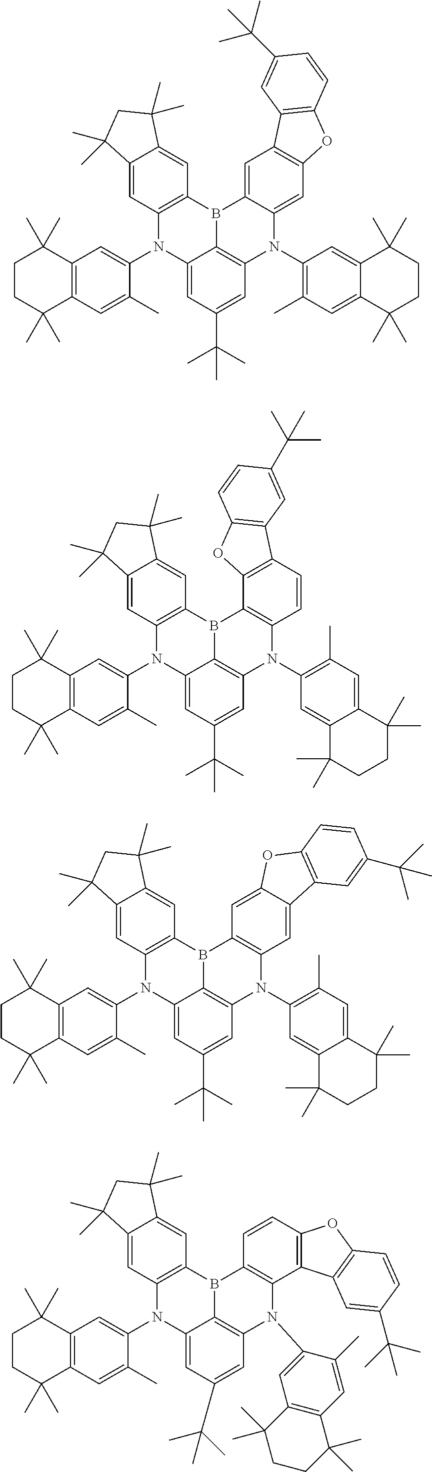

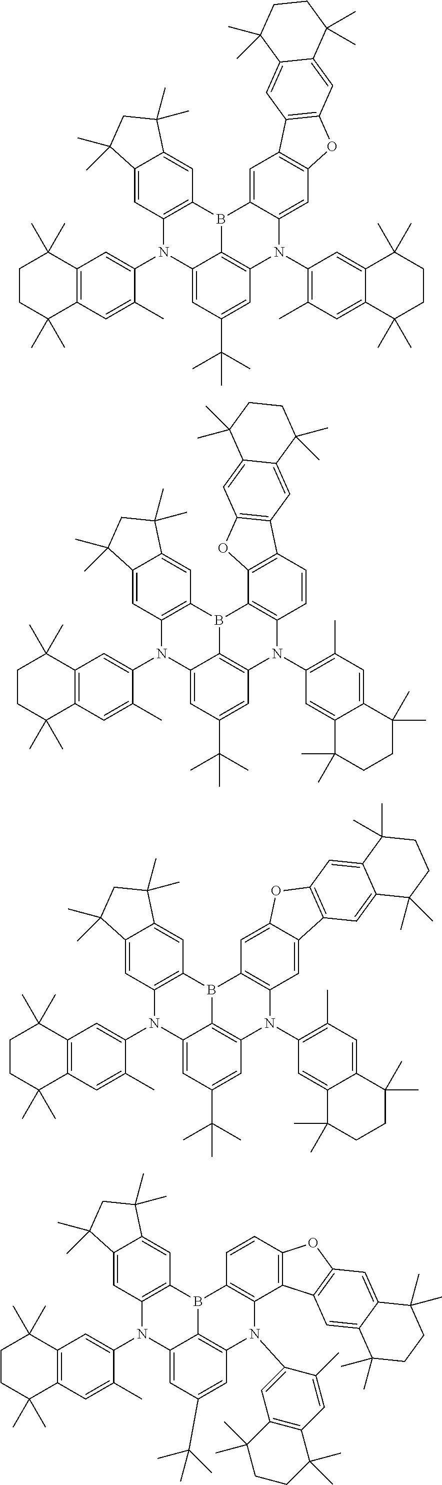

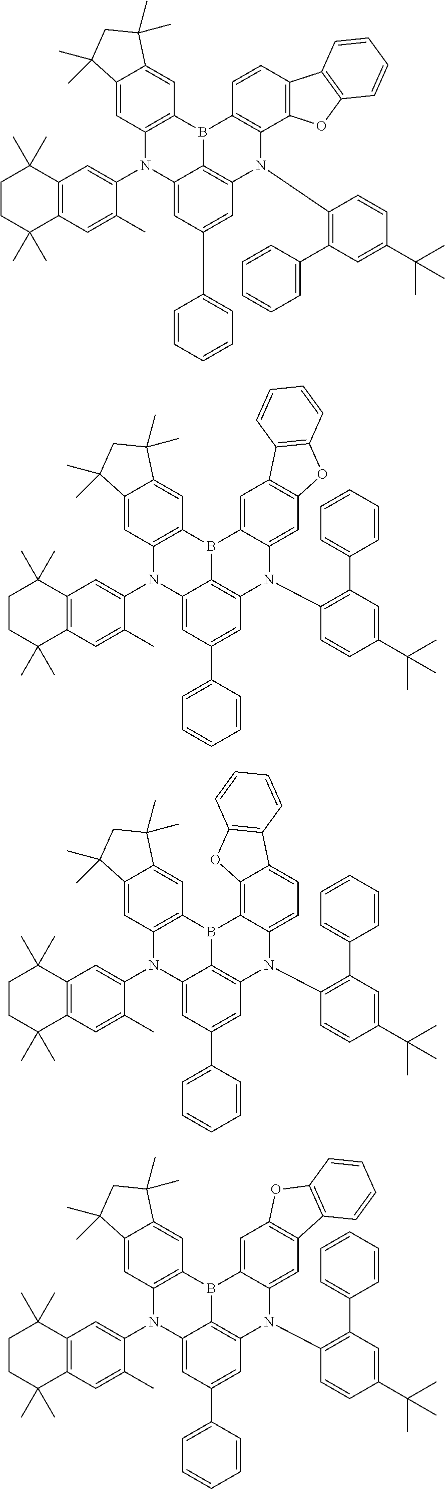

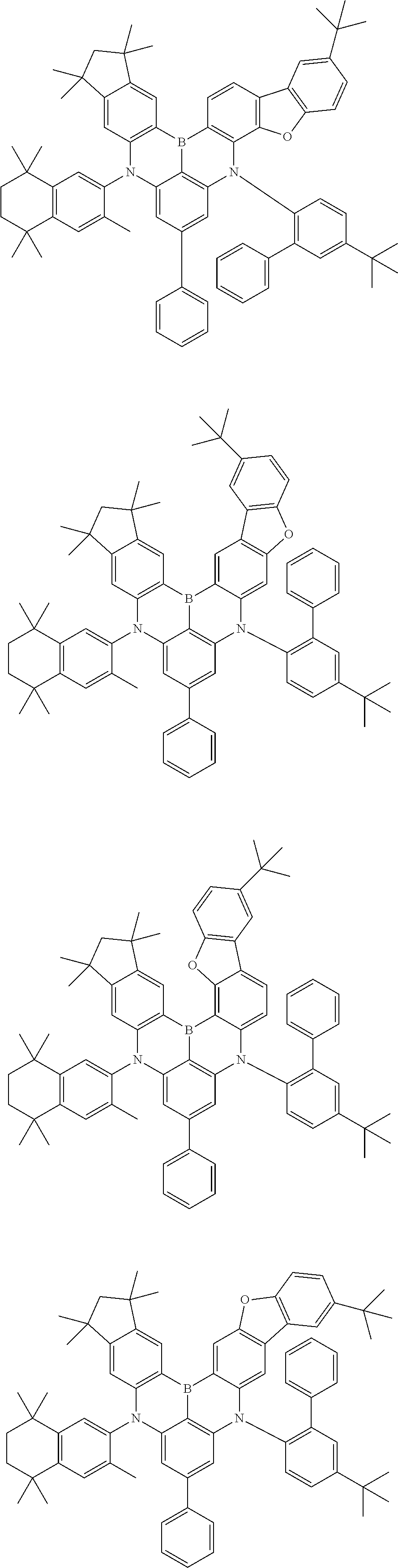

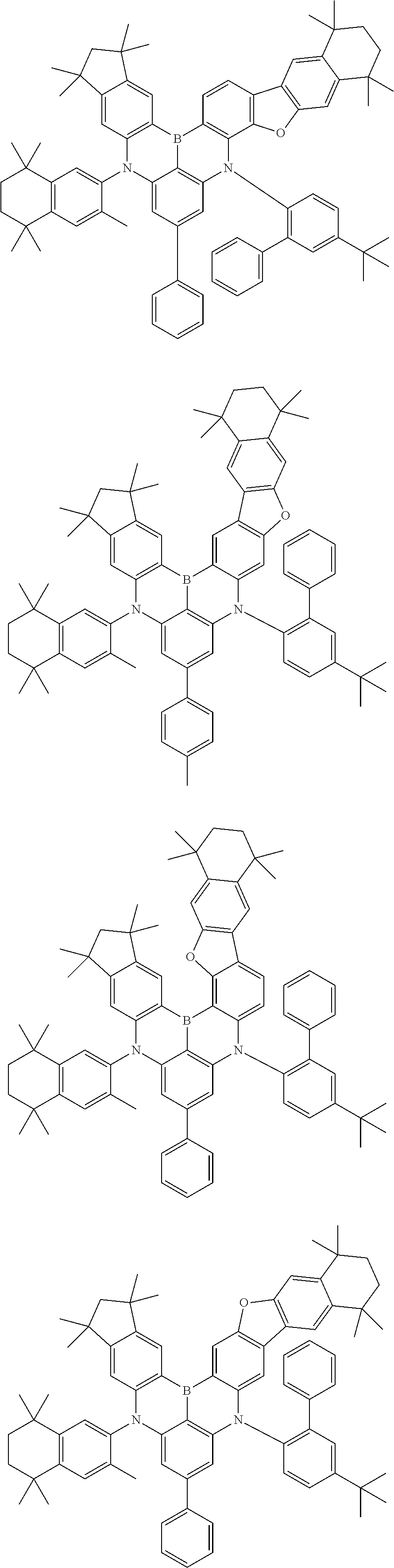

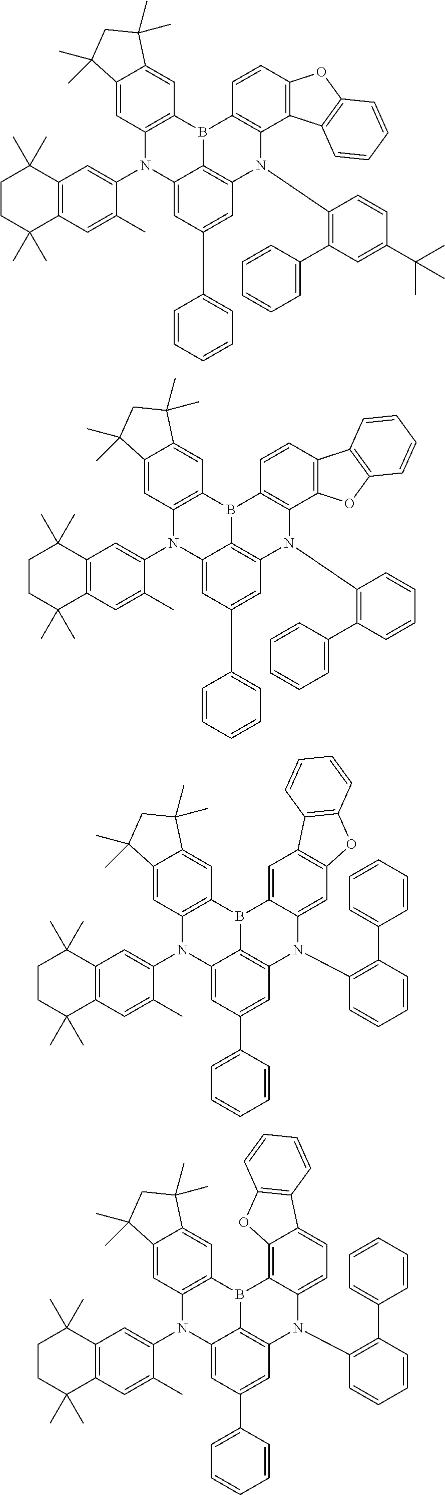

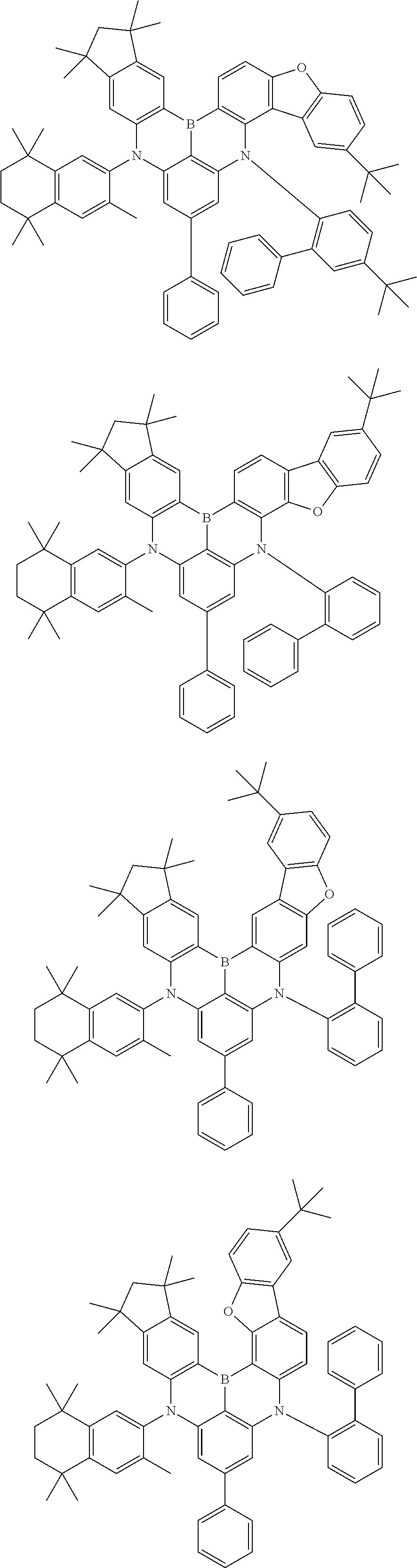

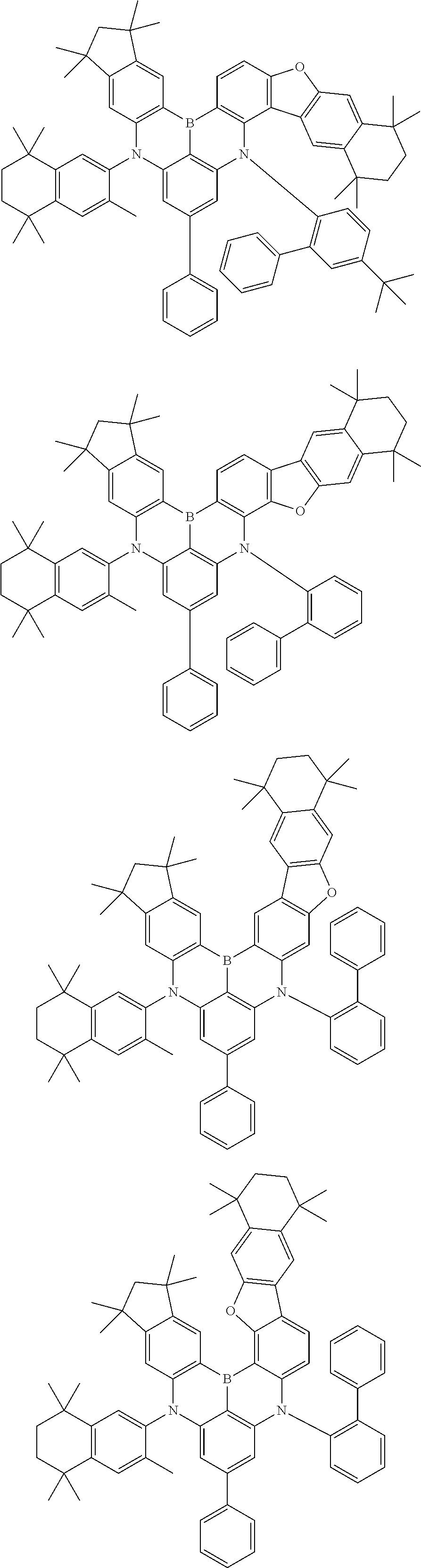

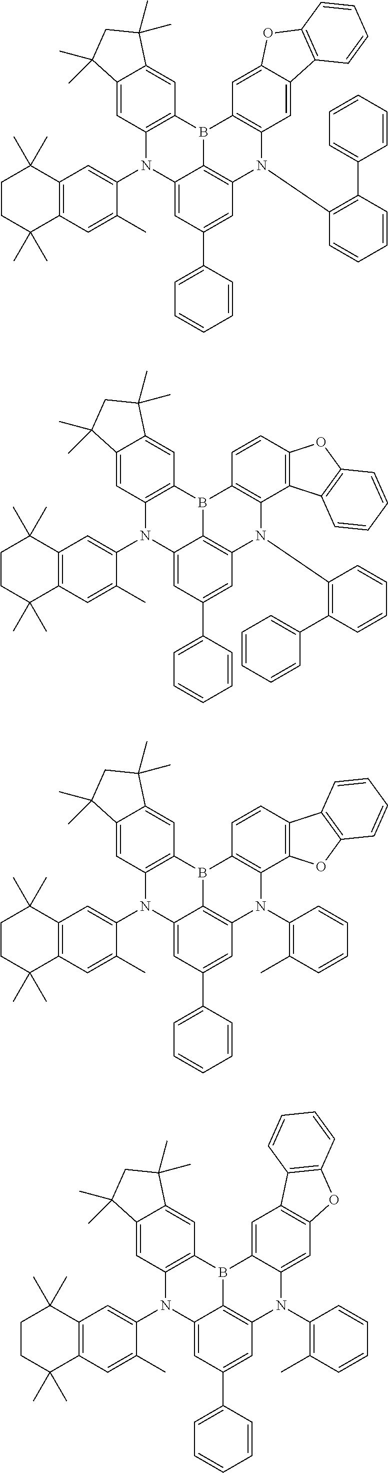 [SMILES: Cc1cc2c(cc1N1c3cc4c(cc3B3c5cc6oc7ccccc7c6cc5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5C)c5cc(-c6ccccc6)cc1c53)C(C)(C)CC4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(-c5ccccc5)cc1c32)C(C)(C)CC4(C)C]

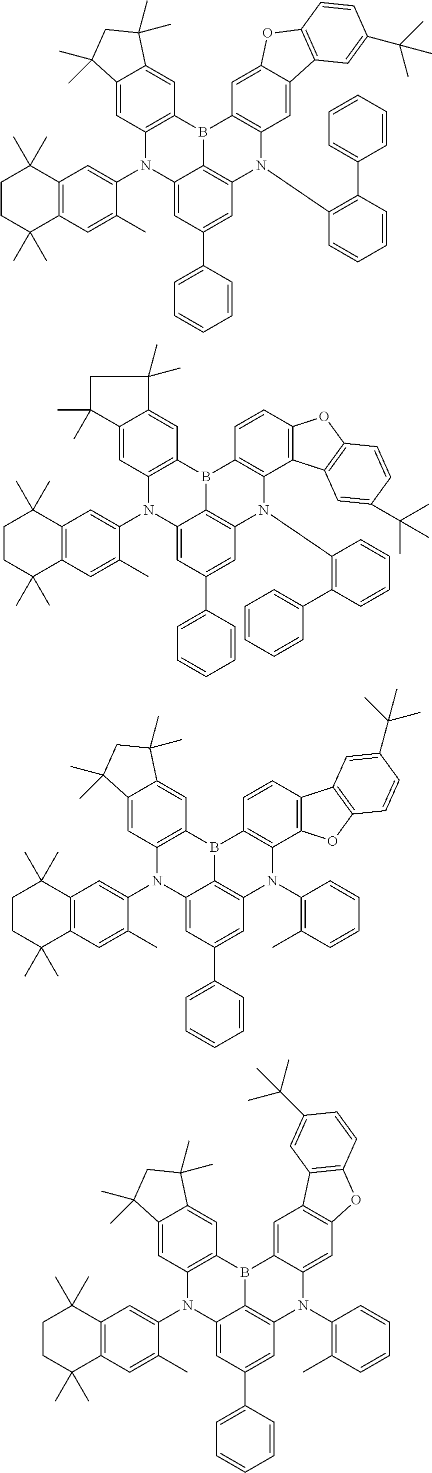

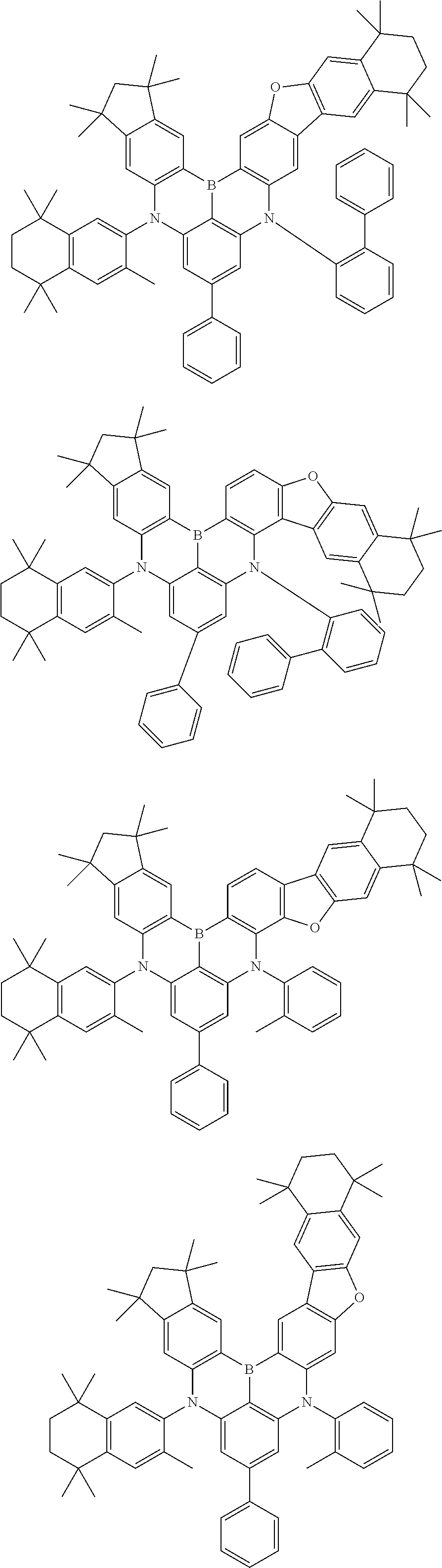

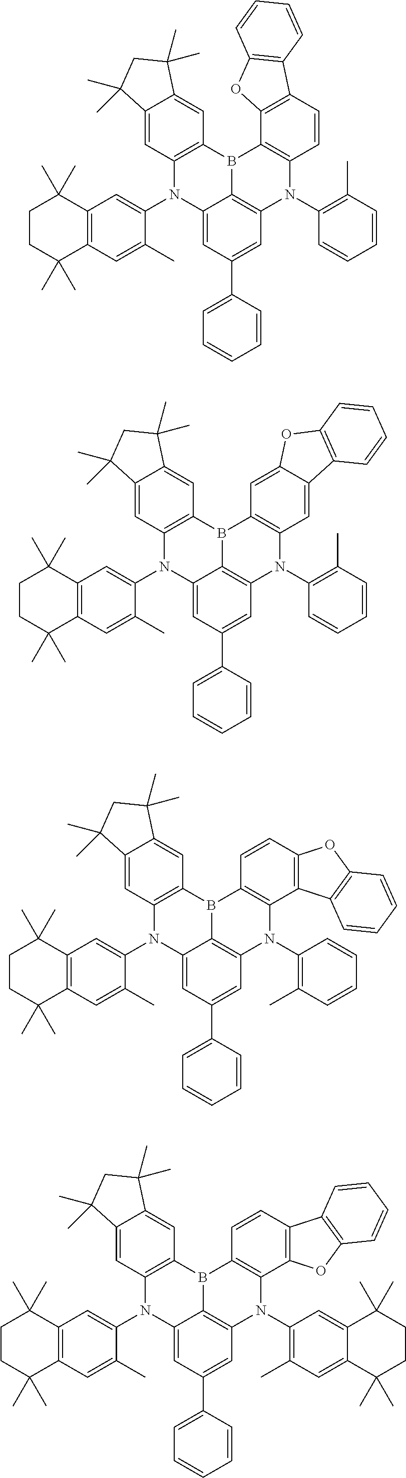 [SMILES: Cc1cc2c(cc1N1c3cc4c(cc3B3c5c1cc(-c1ccccc1)cc5N(c1ccccc1C)c1ccc5c(oc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)oc1ccccc13 ; Cc1cc2c(cc1N1c3cc4c(cc3B3c5ccc6oc7ccccc7c6c5N(c5ccccc5C)c5cc(-c6ccccc6)cc1c53)C(C)(C)CC4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(-c6ccccc6)cc1c53)C(C)(C)CC4(C)C)C(C)(C)CCC2(C)C]

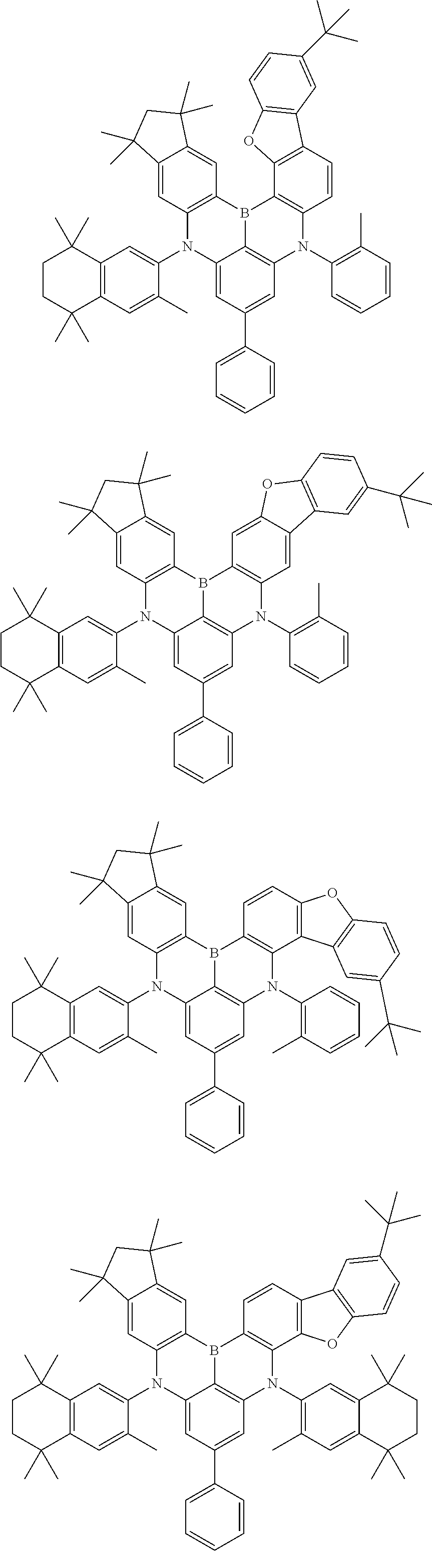

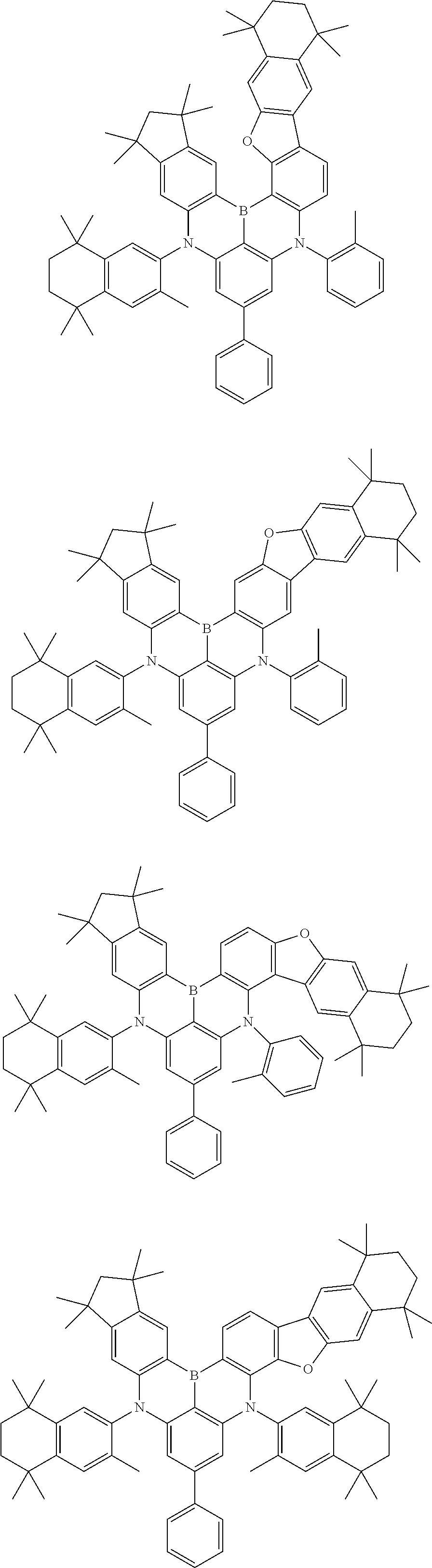

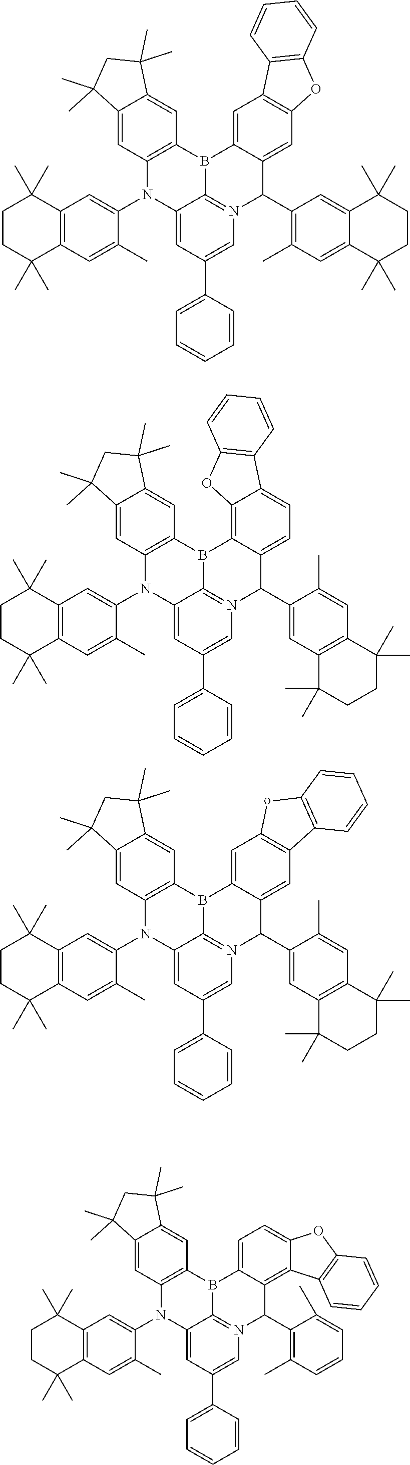

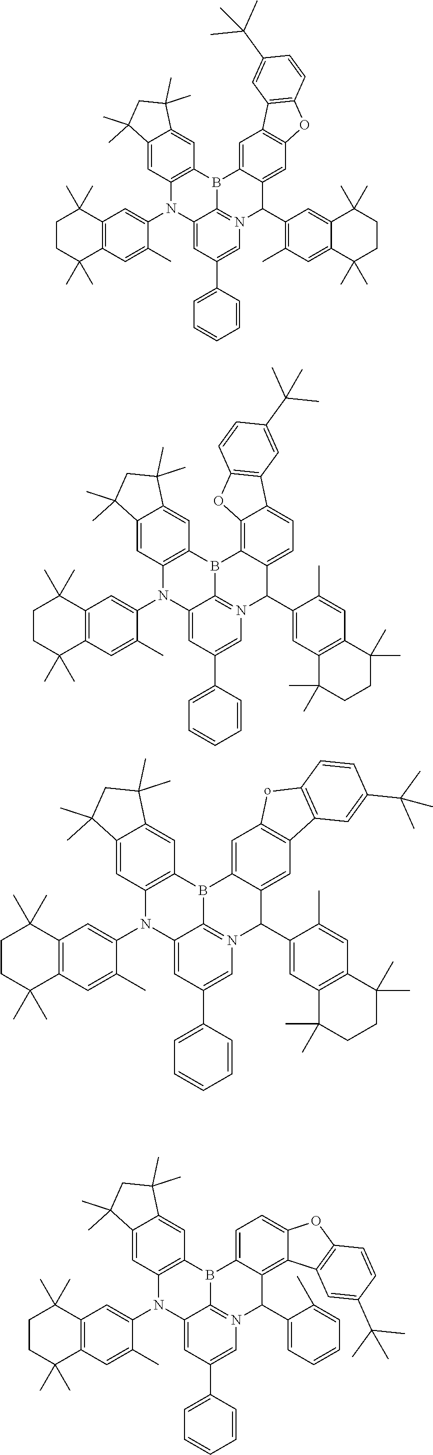

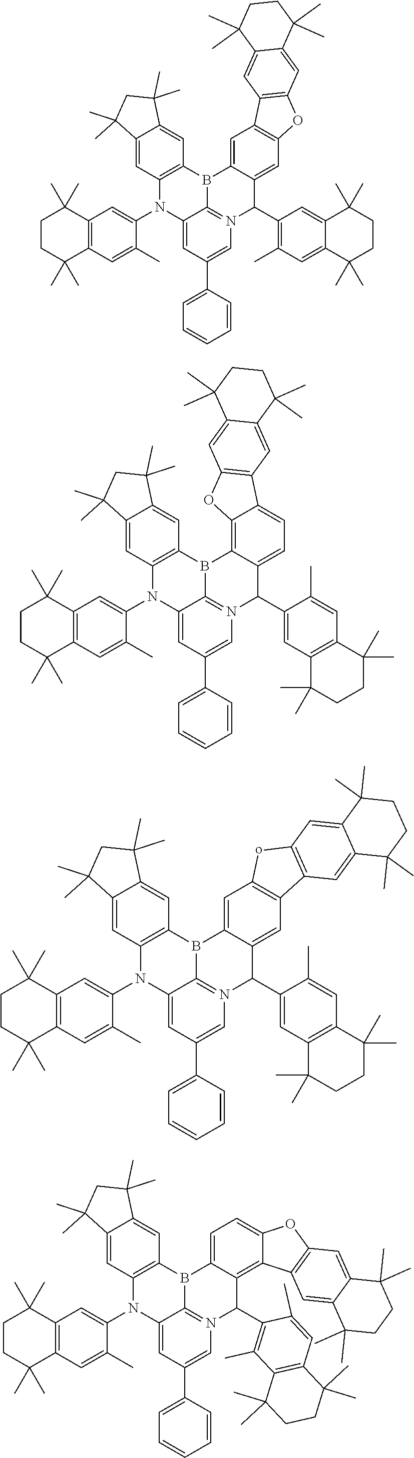

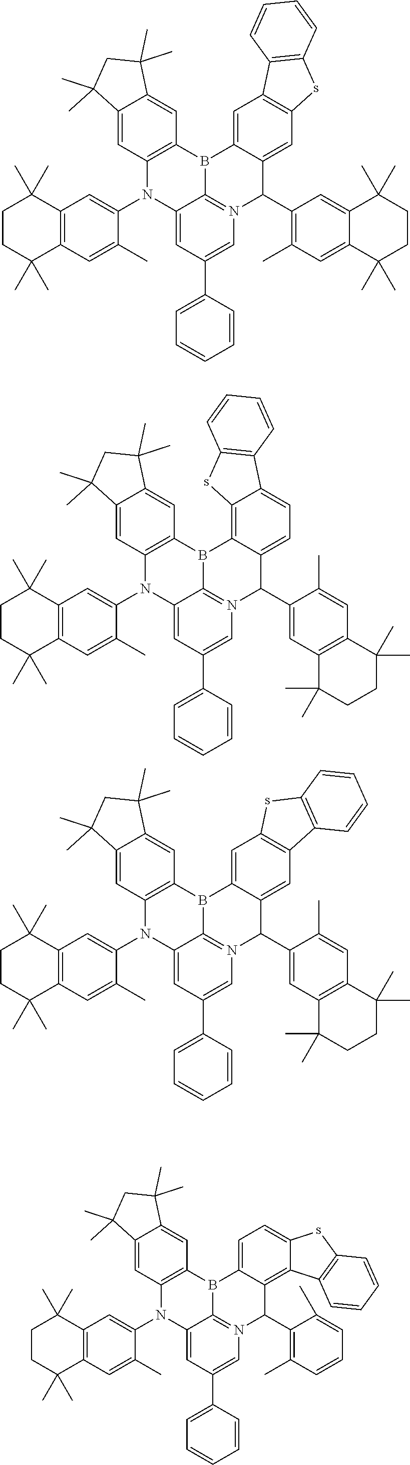

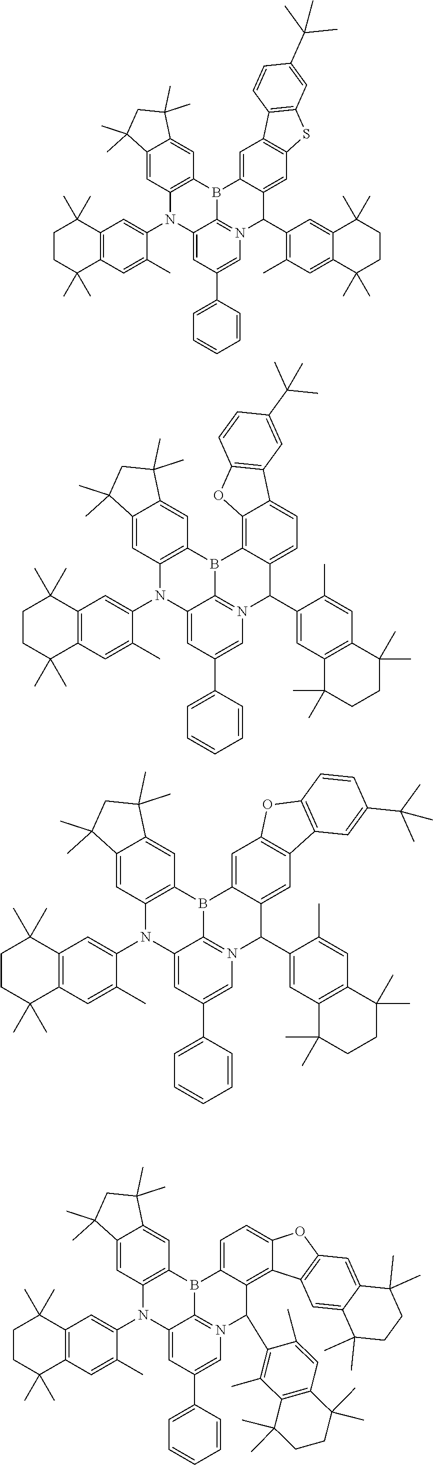

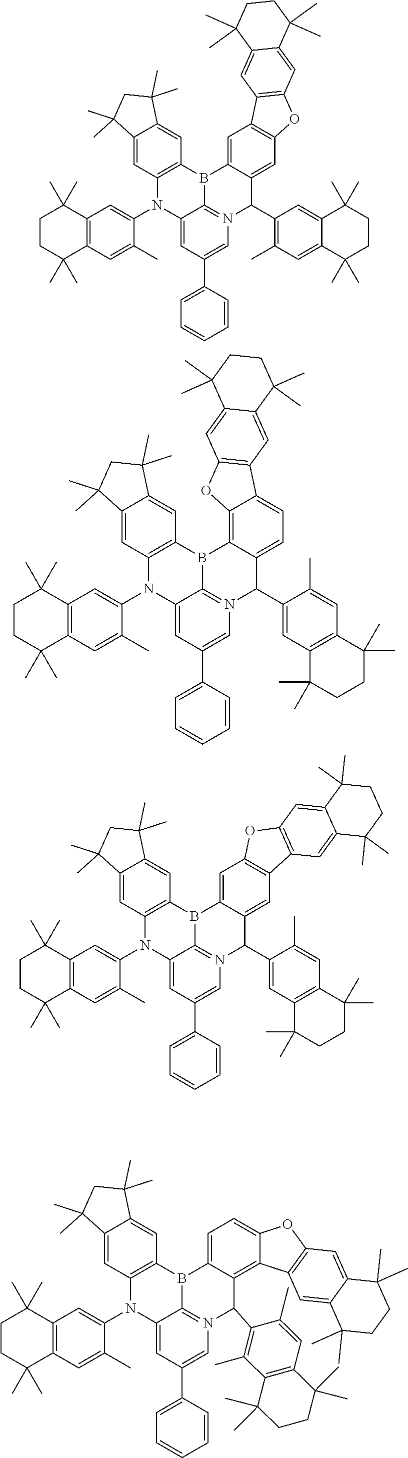

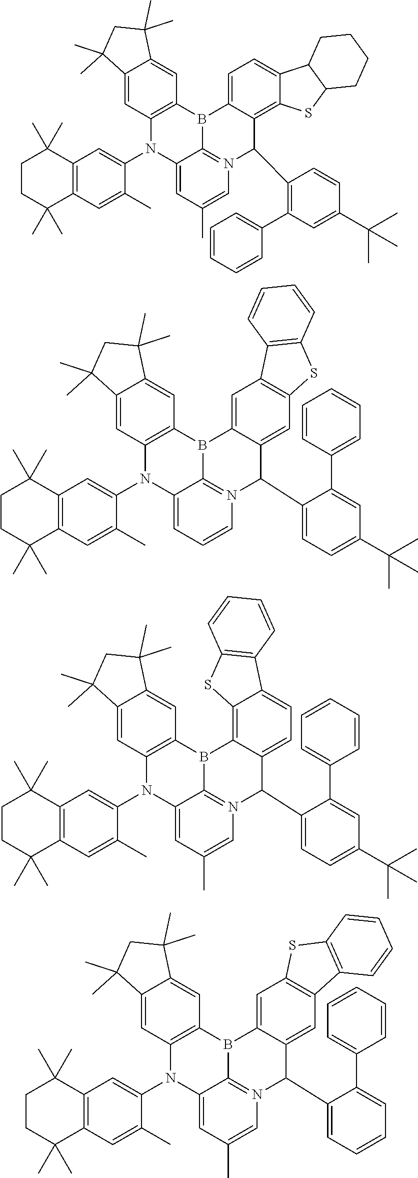

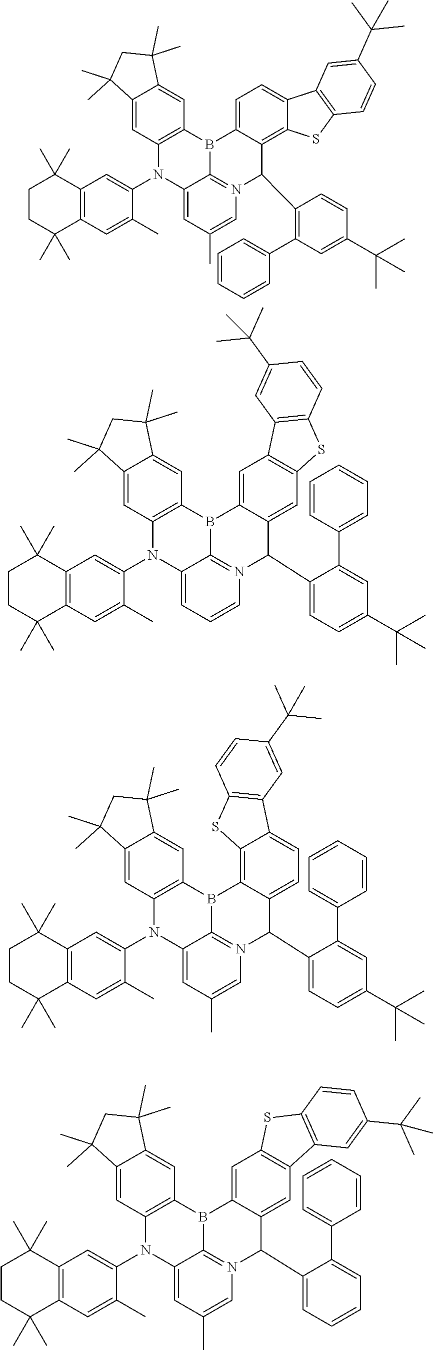

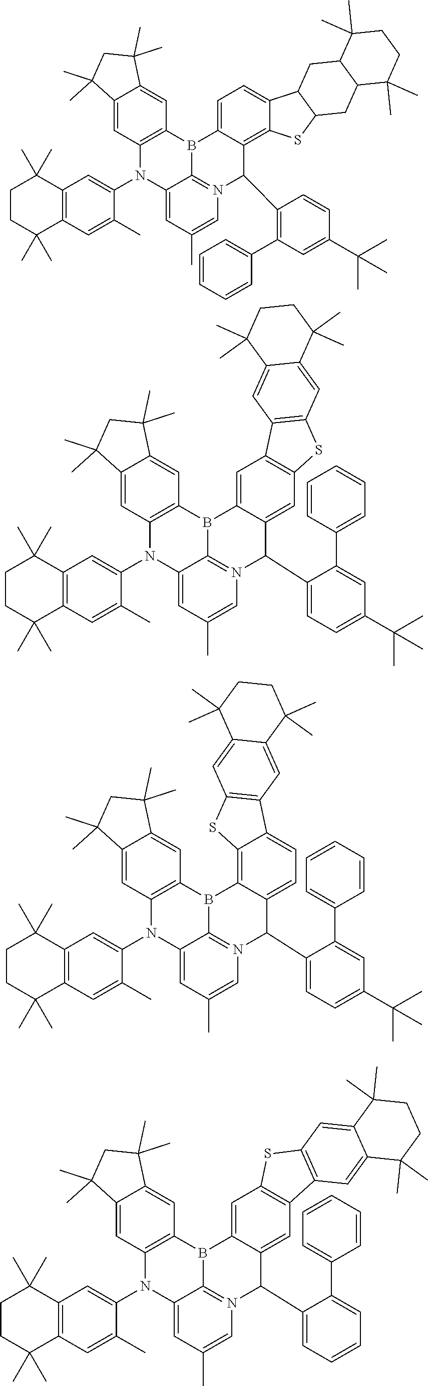

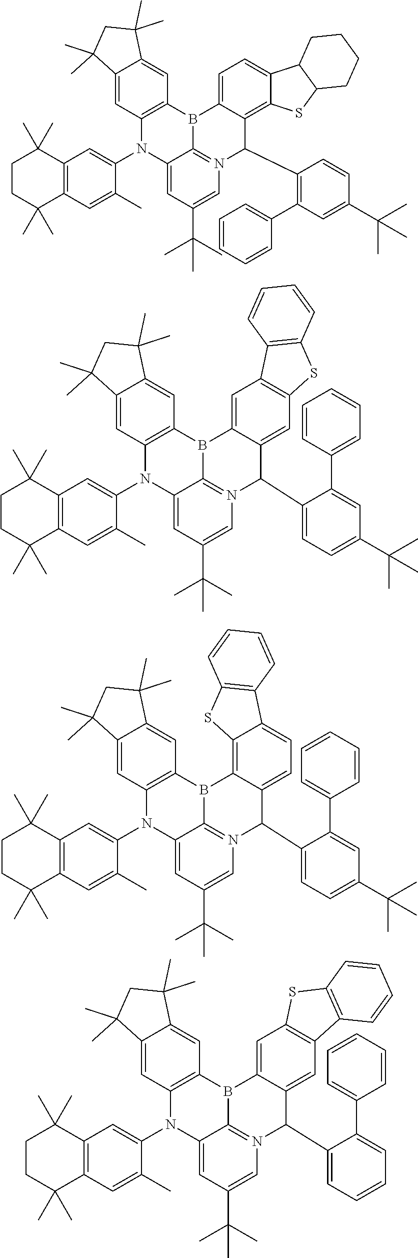

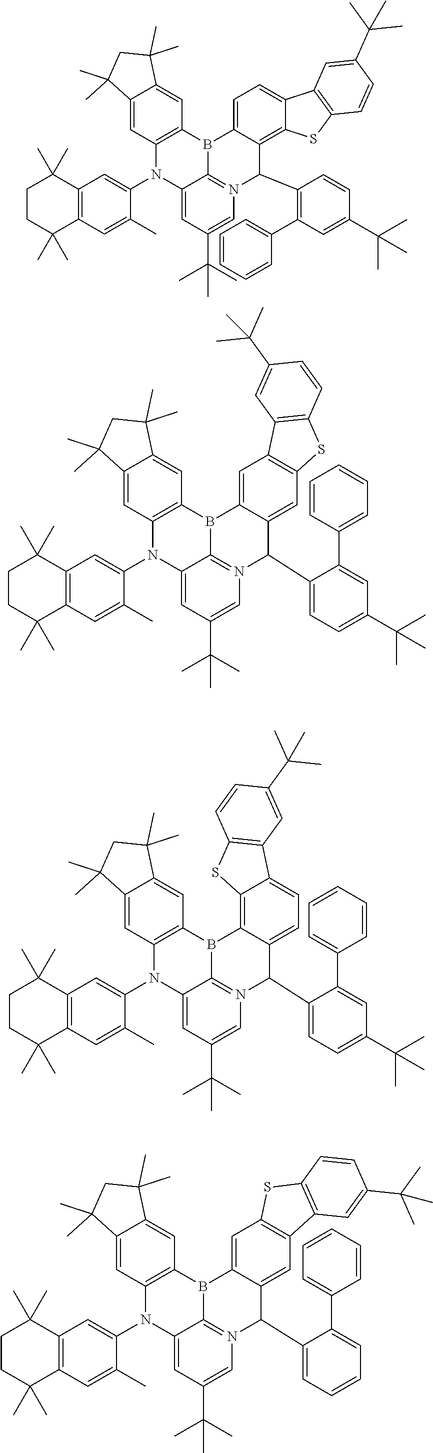

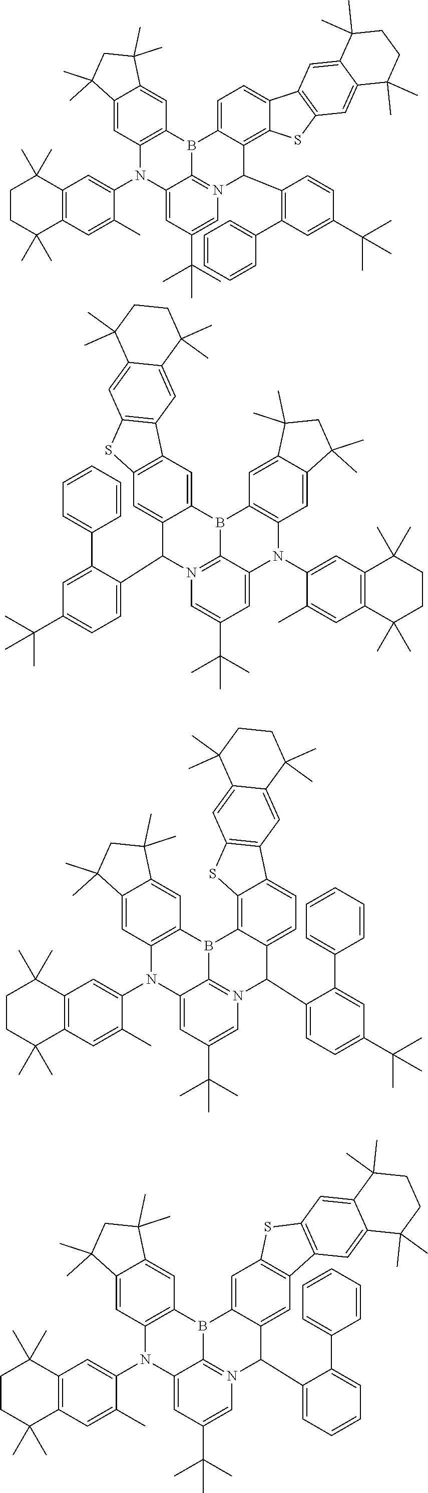

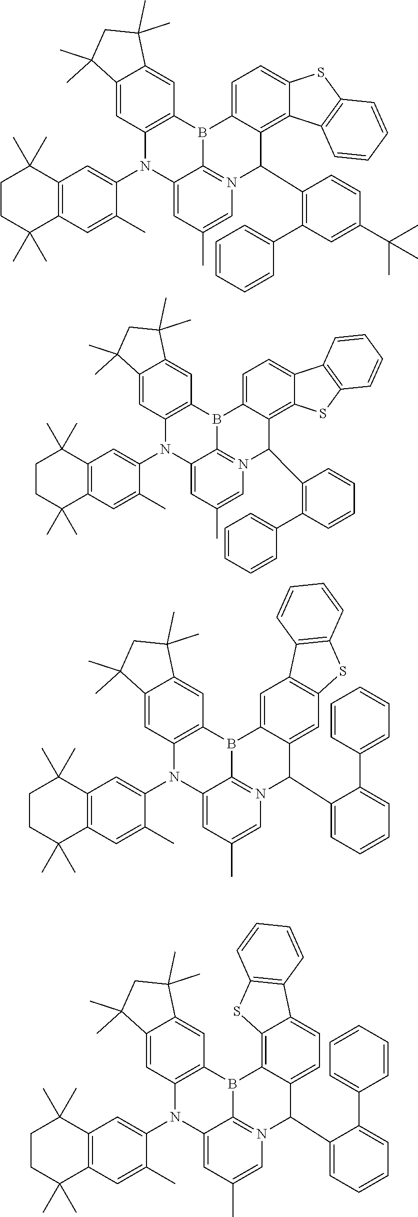

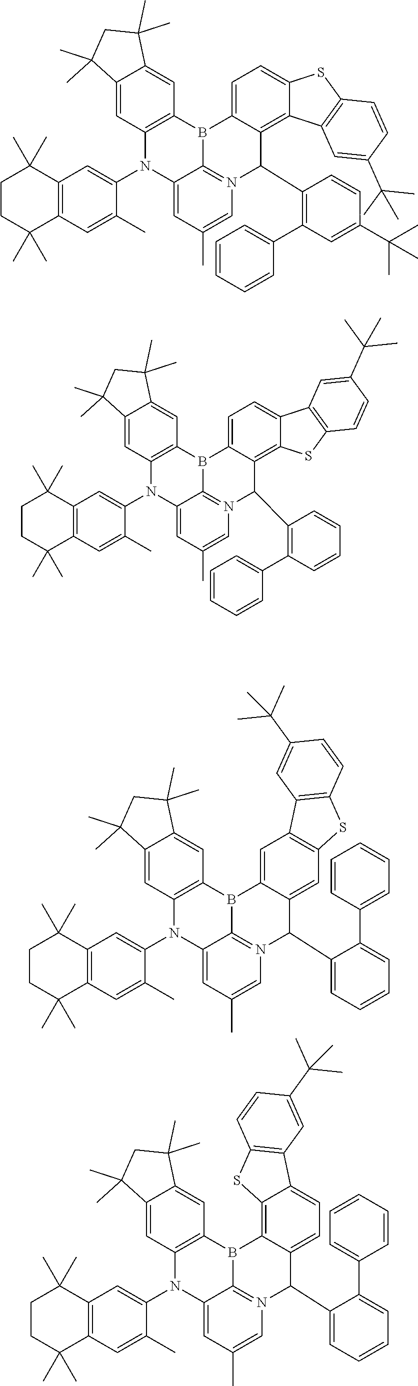

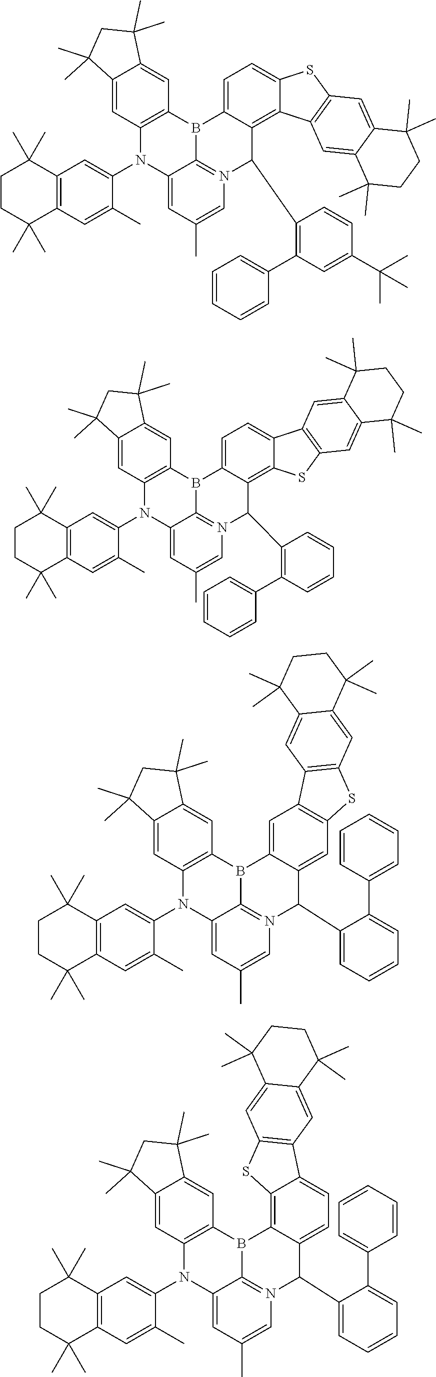

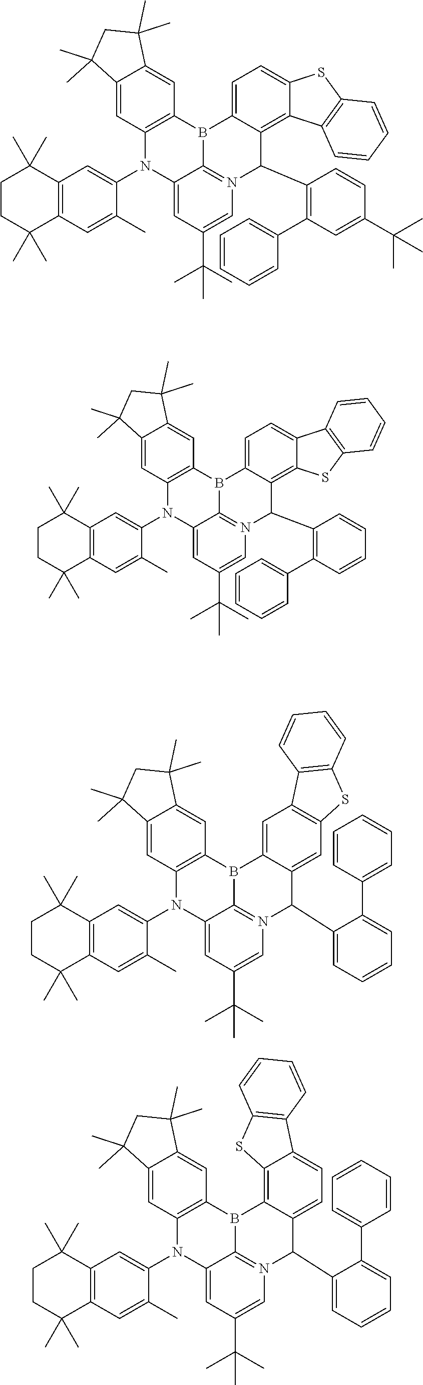

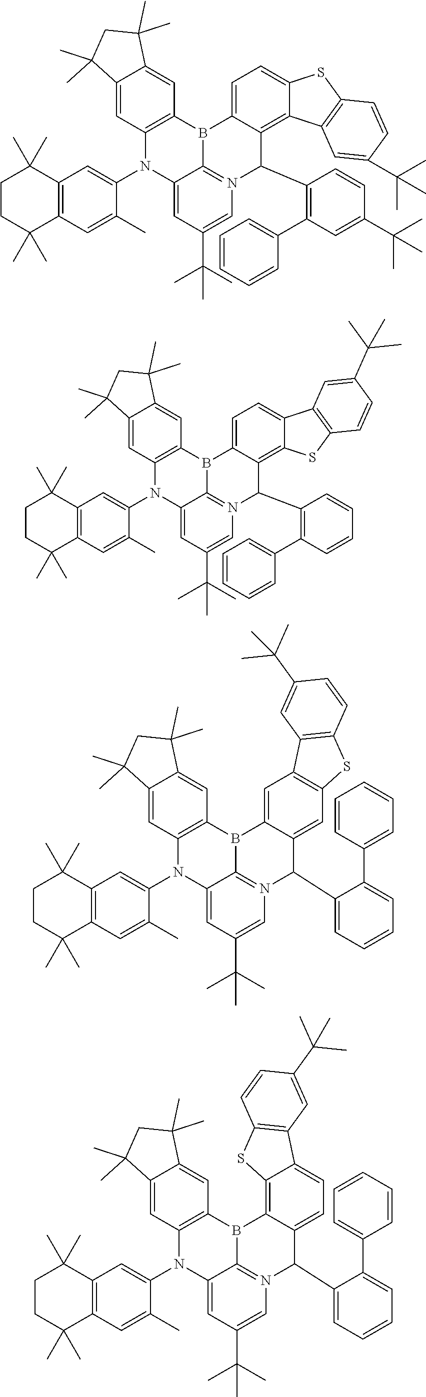

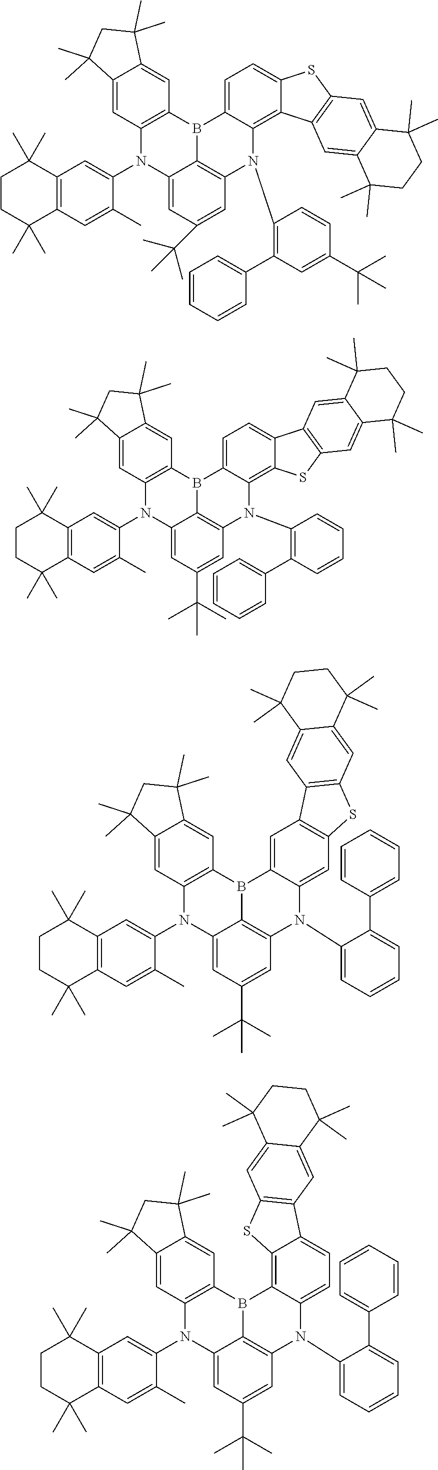

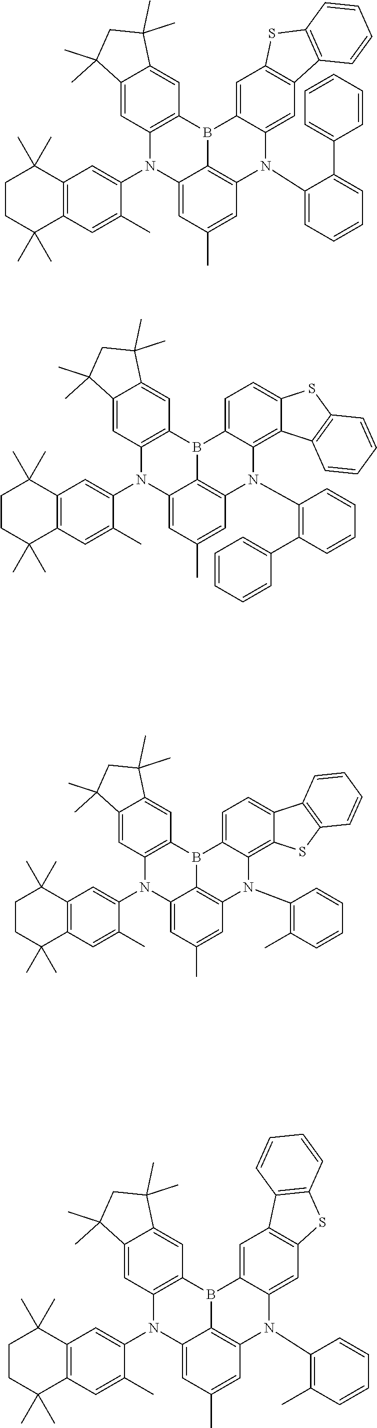 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1ccccc14 ; Cc1cc2c3c(c1)N(c1ccccc1-c1ccccc1)c1c(ccc4sc5ccccc5c14)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)CC3(C)C ; Cc1cc2c3c(c1)N(c1ccccc1C)c1cc4sc5ccccc5c4cc1B3c1cc3c(cc1N2c1cc2c(cc1C)C(C)(C)CCC2(C)C)C(C)(C)CC3(C)C]

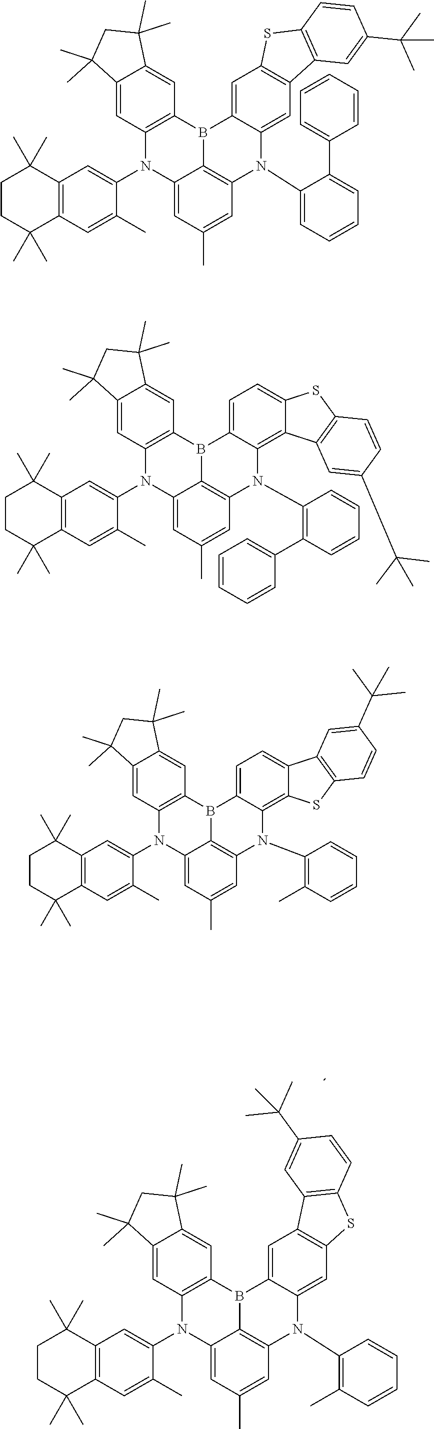

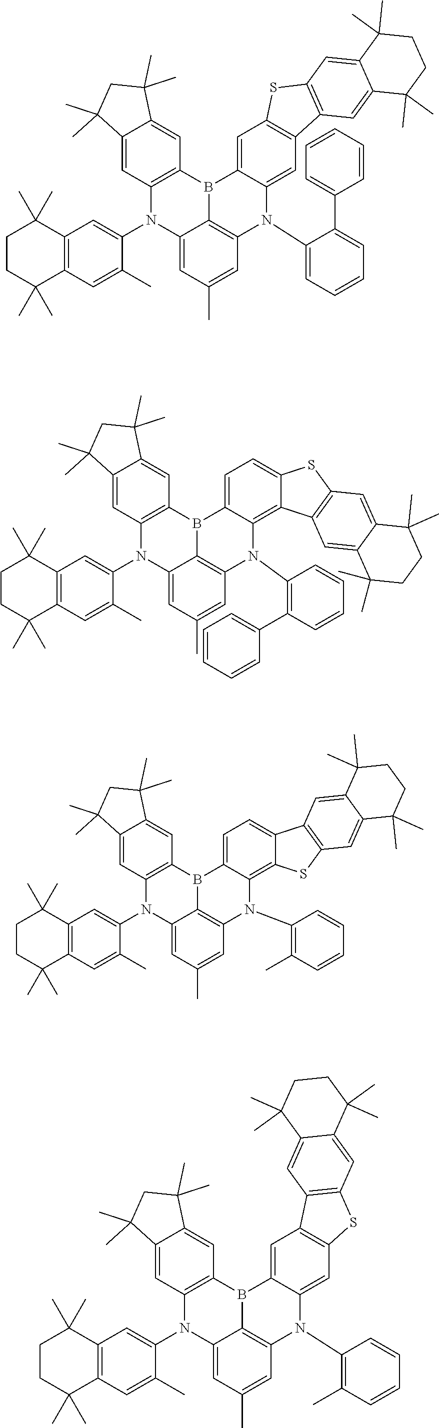

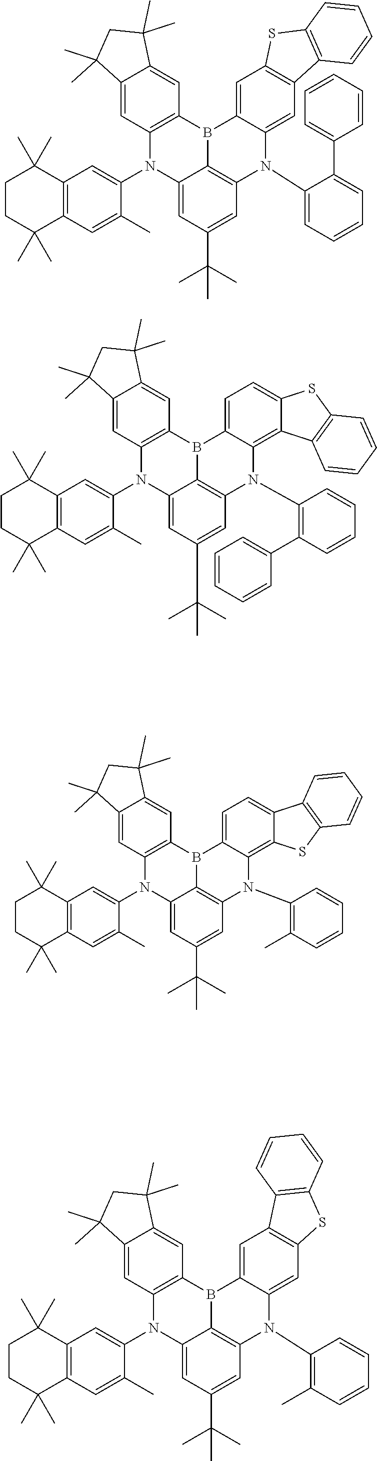 [SMILES: Cc1cc2c(cc1N1c3cc4c(cc3B3c5cc6sc7ccccc7c6cc5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(C(C)(C)C)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5C)c5cc(C(C)(C)C)cc1c53)C(C)(C)CC4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(C(C)(C)C)cc1c32)C(C)(C)CC4(C)C]

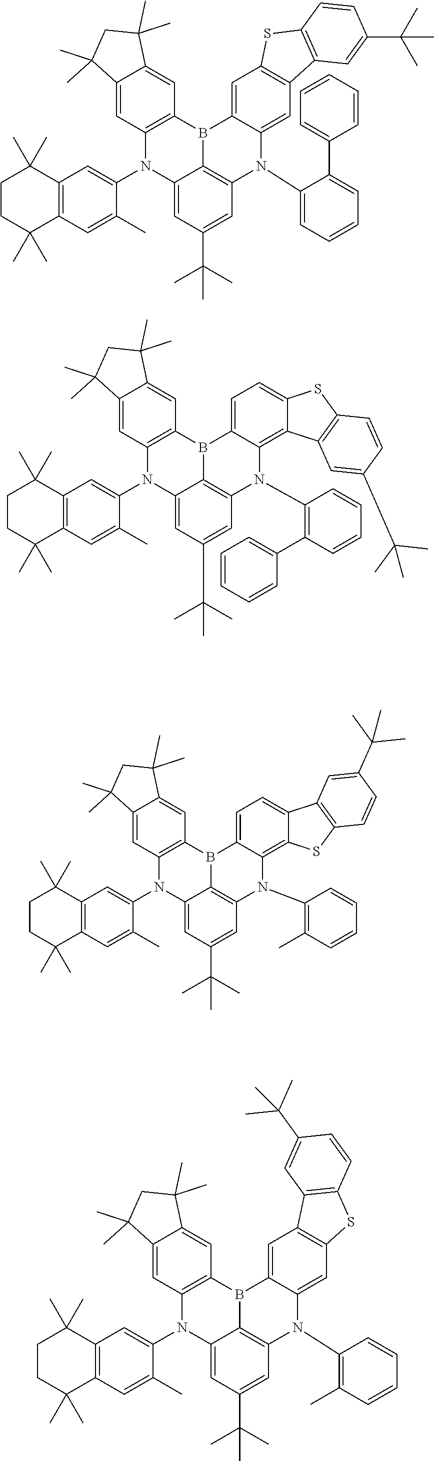

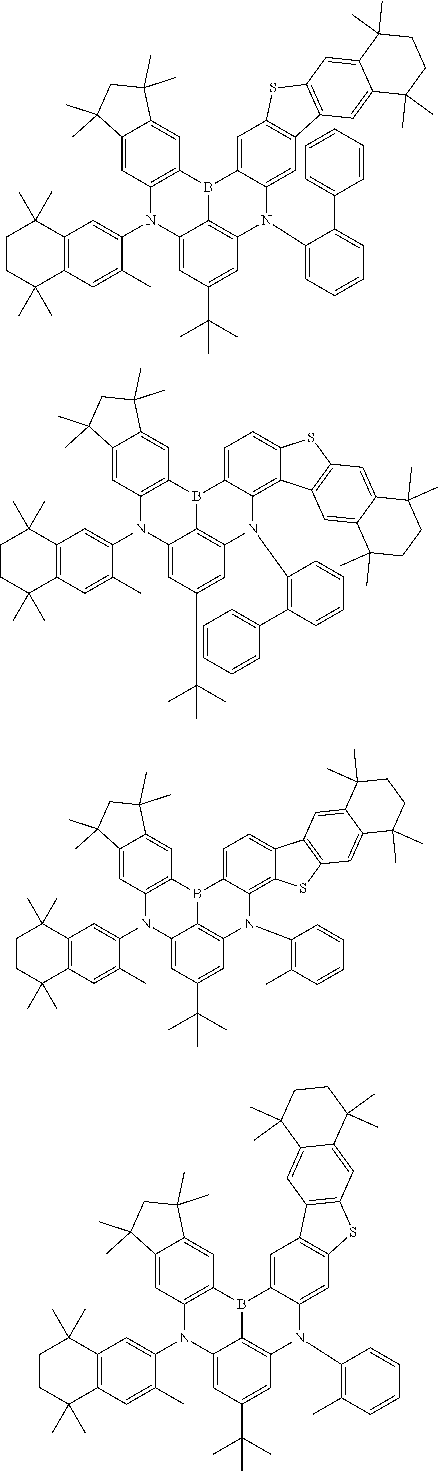

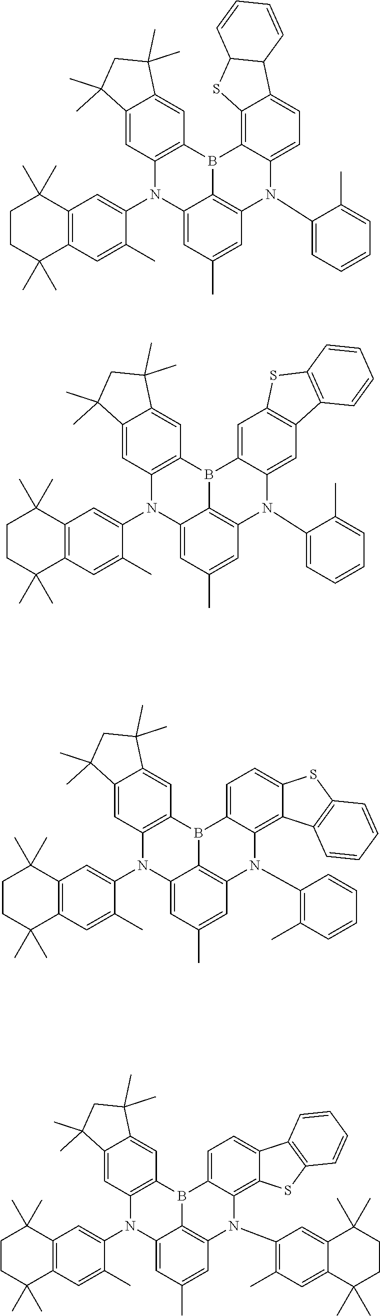 [SMILES: Cc1cc2c3c(c1)N(c1ccccc1C)c1ccc4c(c1B3c1cc3c(cc1N2c1cc2c(cc1C)C(C)(C)CCC2(C)C)C(C)(C)CC3(C)C)SC1C=CC=CC41 ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1ccccc14 ; Cc1cc2c3c(c1)N(c1ccccc1C)c1c(ccc4sc5ccccc5c14)B3c1cc3c(cc1N2c1cc2c(cc1C)C(C)(C)CCC2(C)C)C(C)(C)CC3(C)C ; Cc1cc2c3c(c1)N(c1cc4c(cc1C)C(C)(C)CCC4(C)C)c1c(ccc4c1sc1ccccc14)B3c1cc3c(cc1N2c1cc2c(cc1C)C(C)(C)CCC2(C)C)C(C)(C)CC3(C)C]

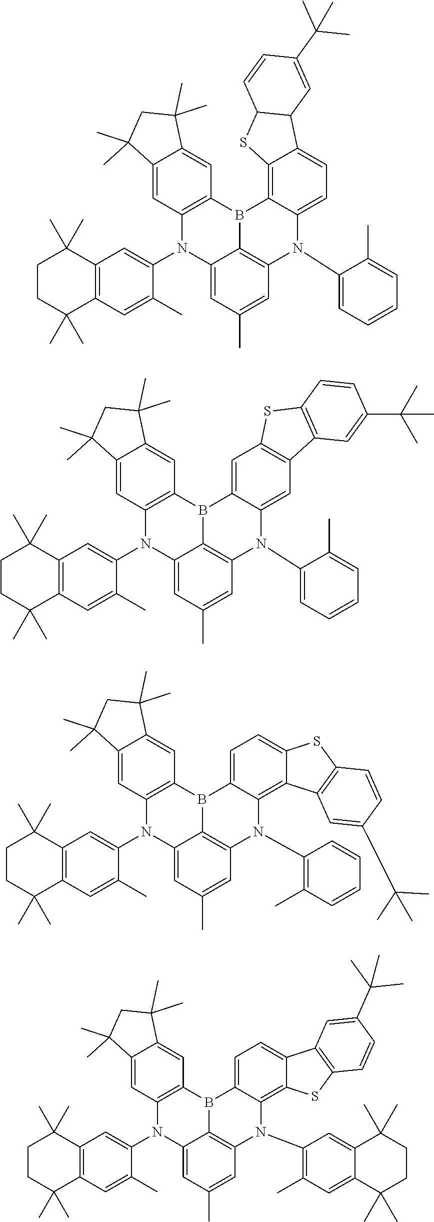

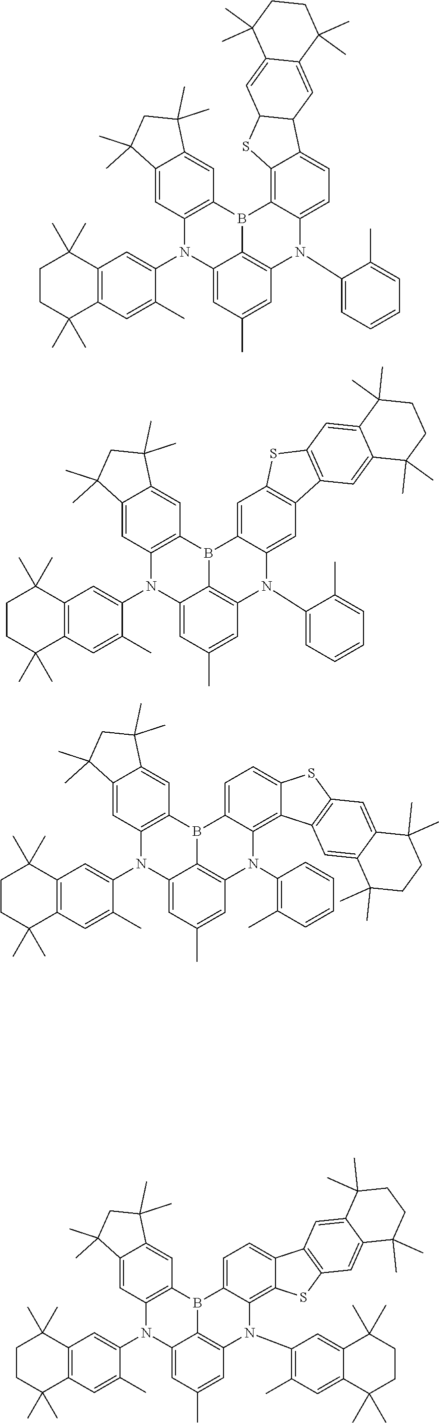

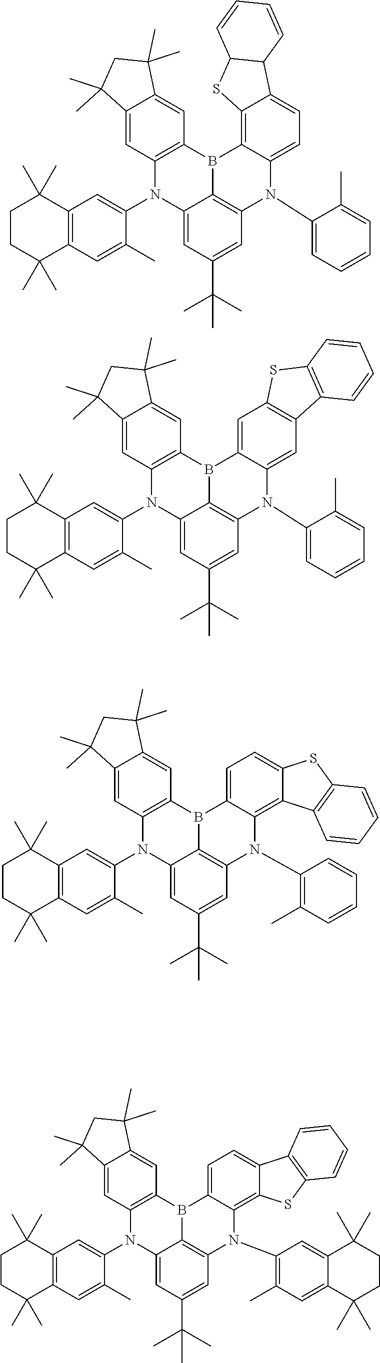

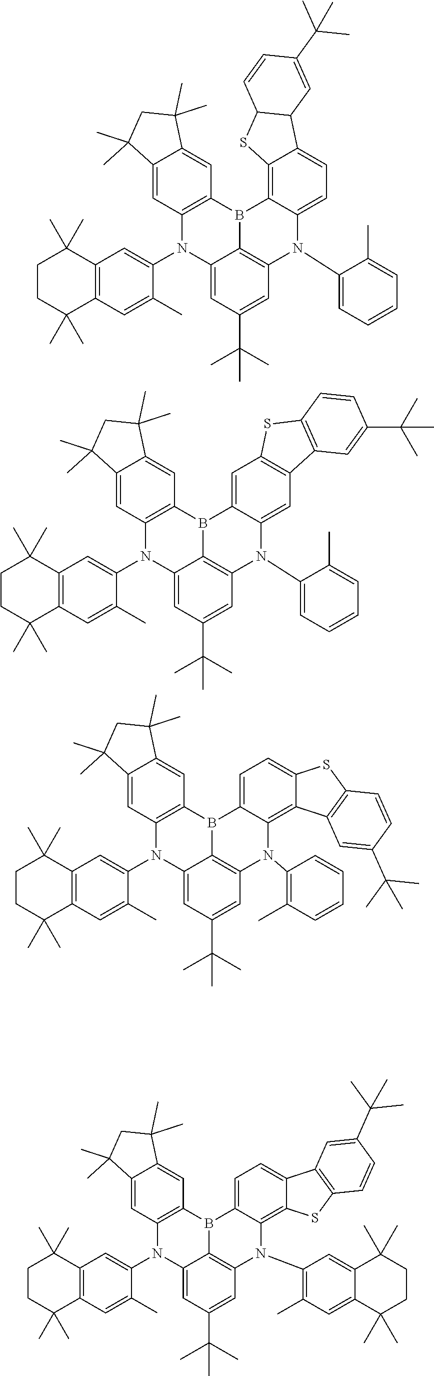

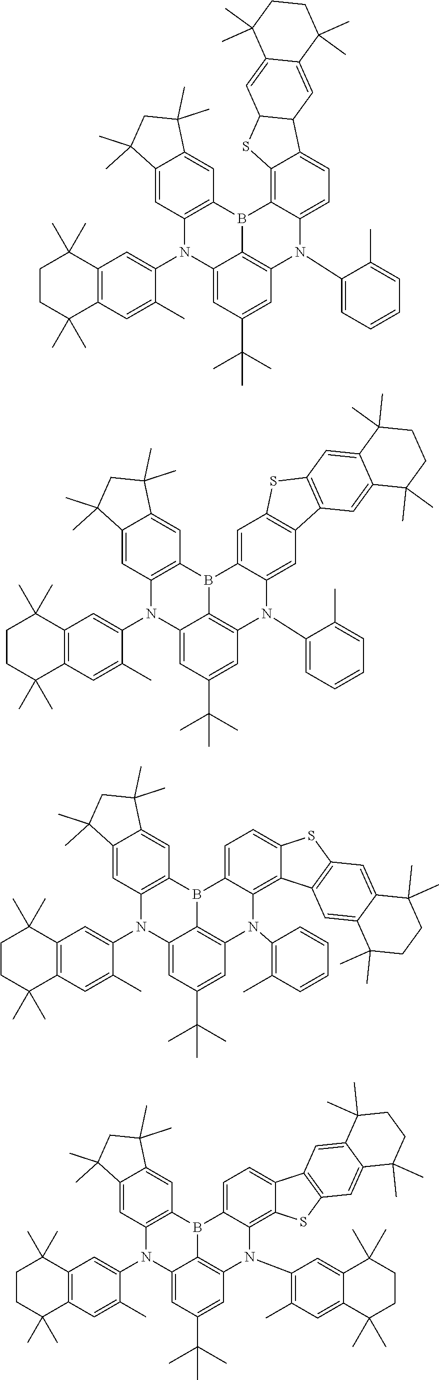

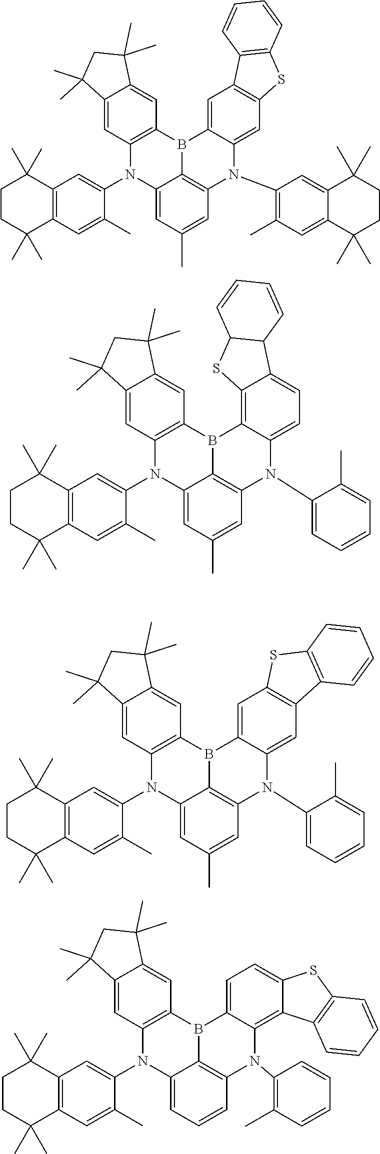 [SMILES: Cc1cc2c3c(c1)N(c1cc4c(cc1C)C(C)(C)CCC4(C)C)c1cc4sc5ccccc5c4cc1B3c1cc3c(cc1N2c1cc2c(cc1C)C(C)(C)CCC2(C)C)C(C)(C)CC3(C)C ; Cc1cc2c3c(c1)N(c1ccccc1C)c1ccc4c(c1B3c1cc3c(cc1N2c1cc2c(cc1C)C(C)(C)CCC2(C)C)C(C)(C)CC3(C)C)SC1C=CC=CC41 ; Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1ccccc14 ; Cc1cc2c(cc1N1c3cc4c(cc3B3c5ccc6sc7ccccc7c6c5N(c5ccccc5C)c5cccc1c53)C(C)(C)CC4(C)C)C(C)(C)CCC2(C)C]

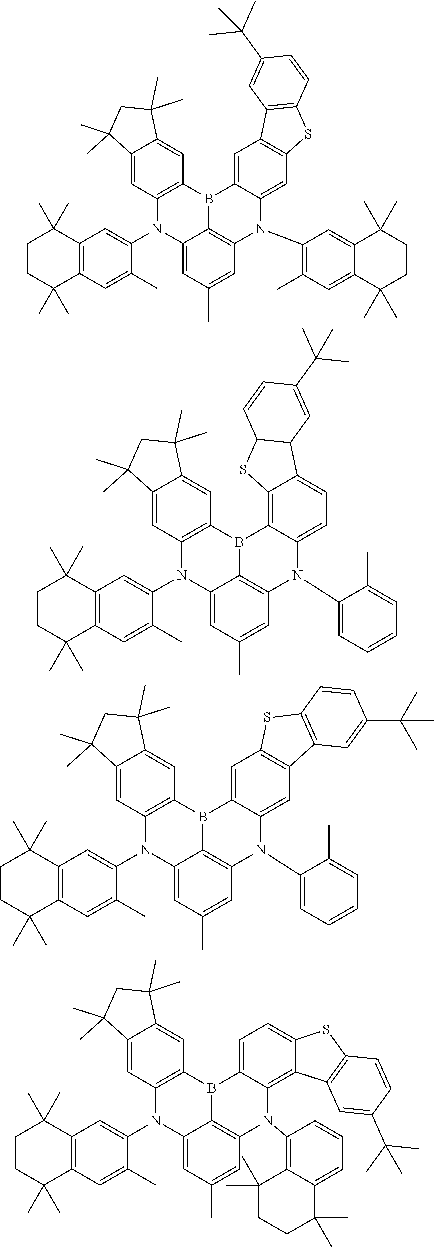

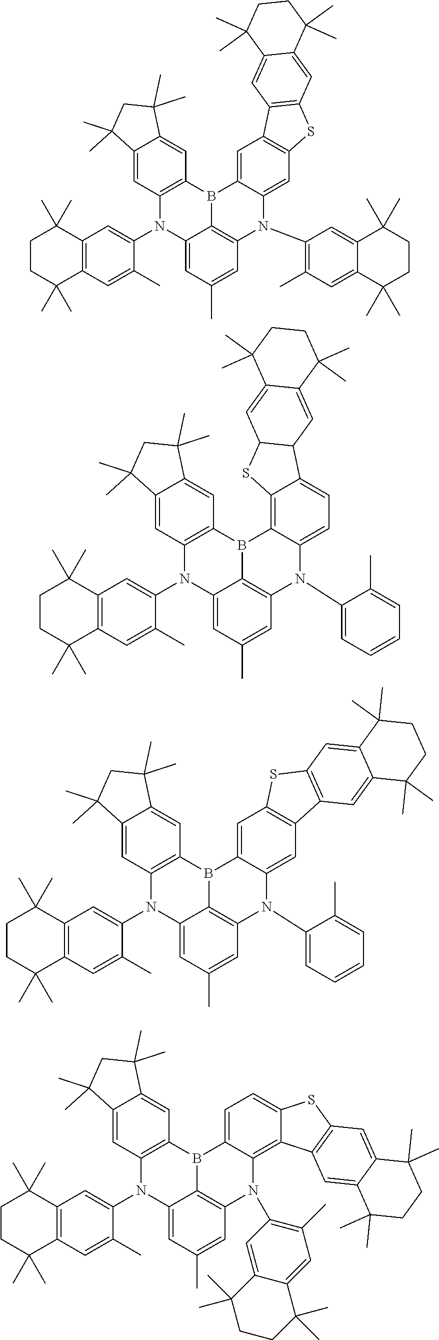

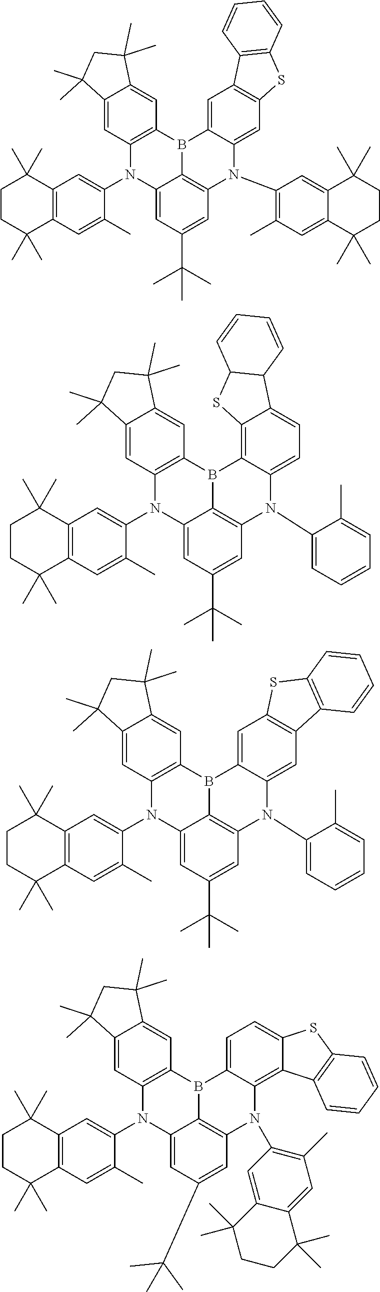

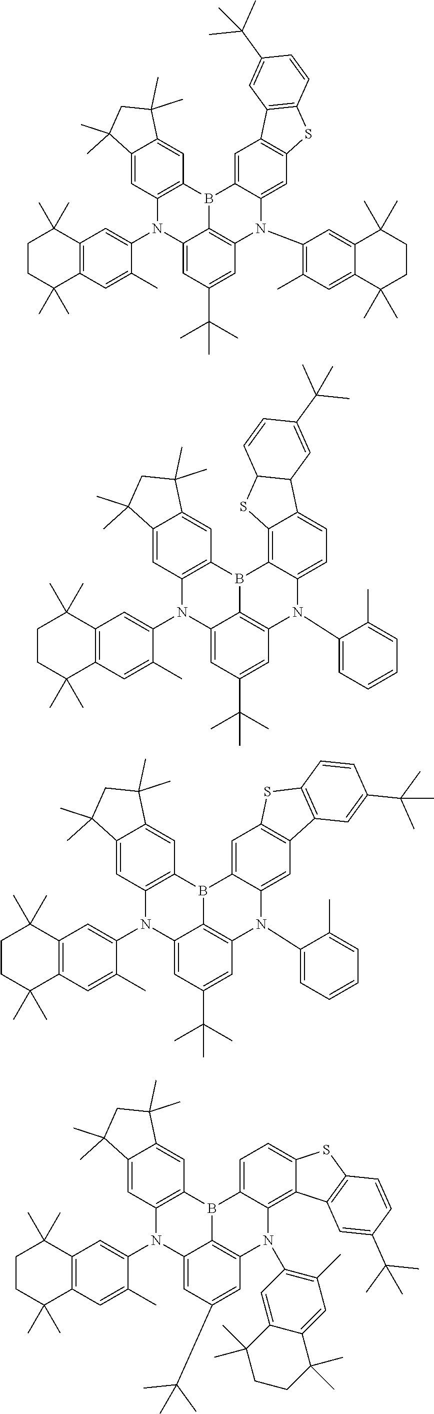

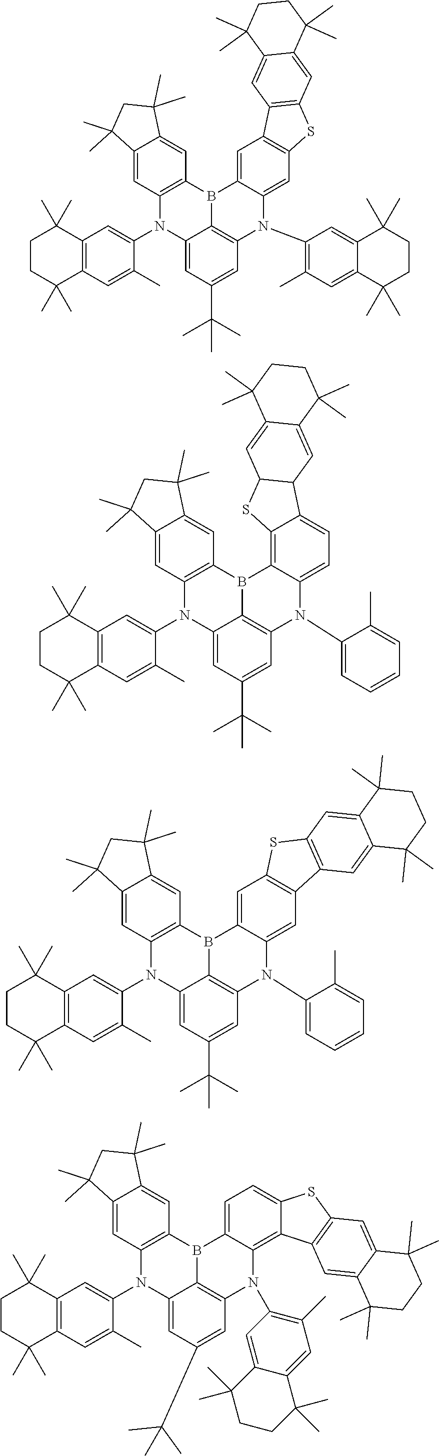

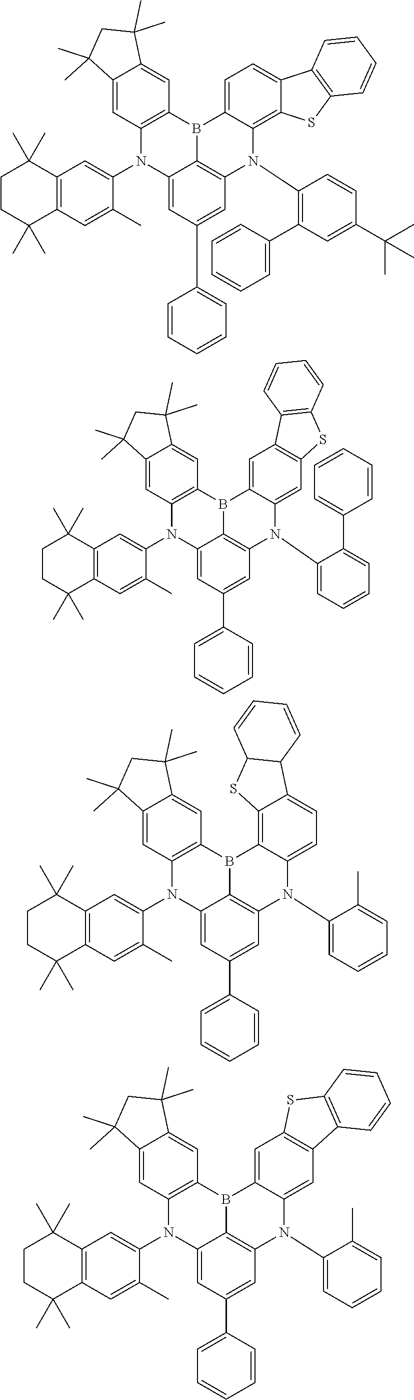

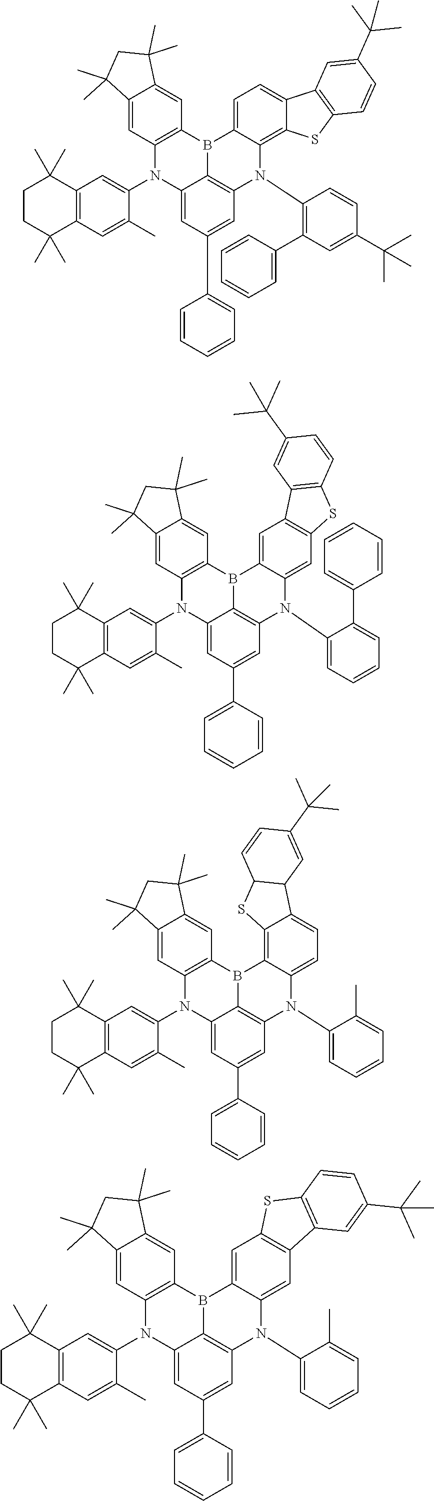

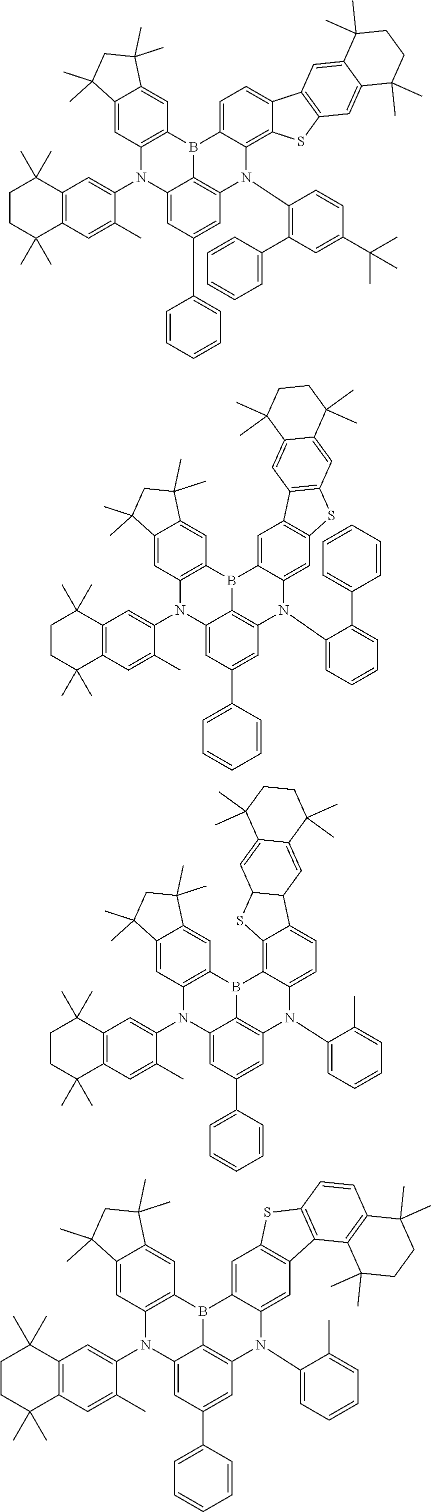

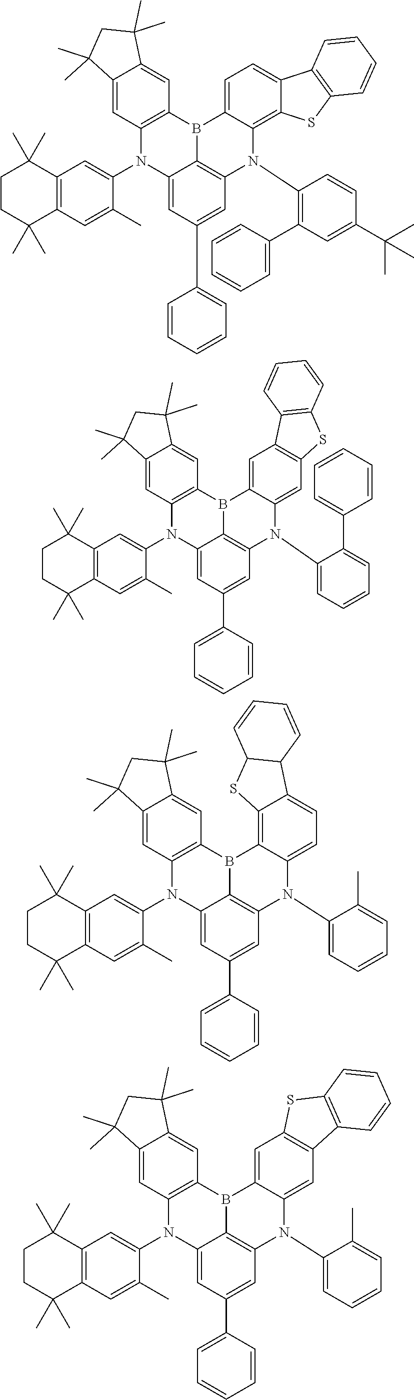

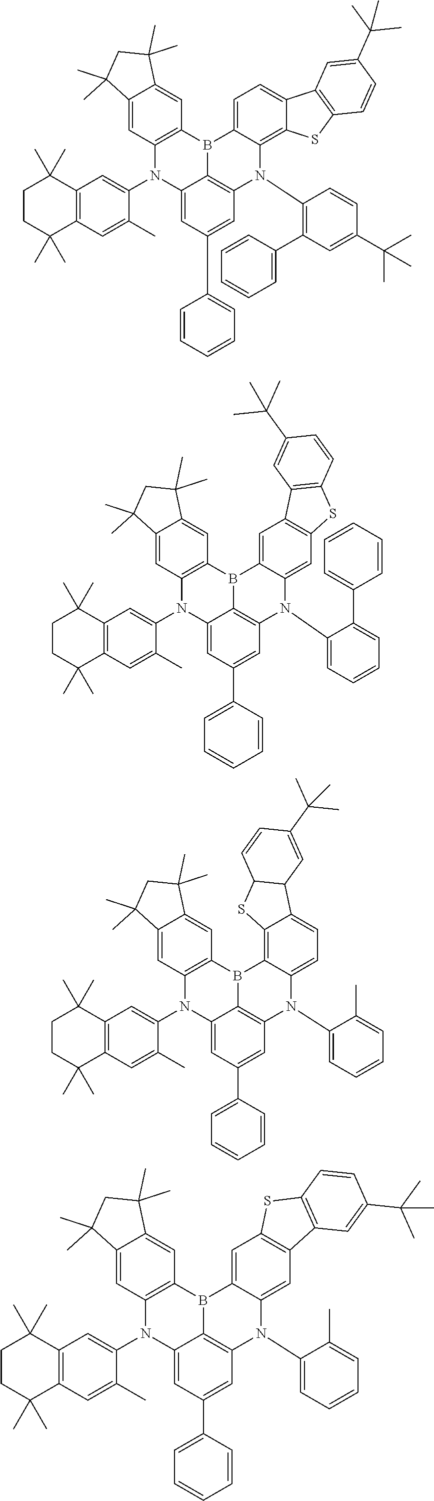

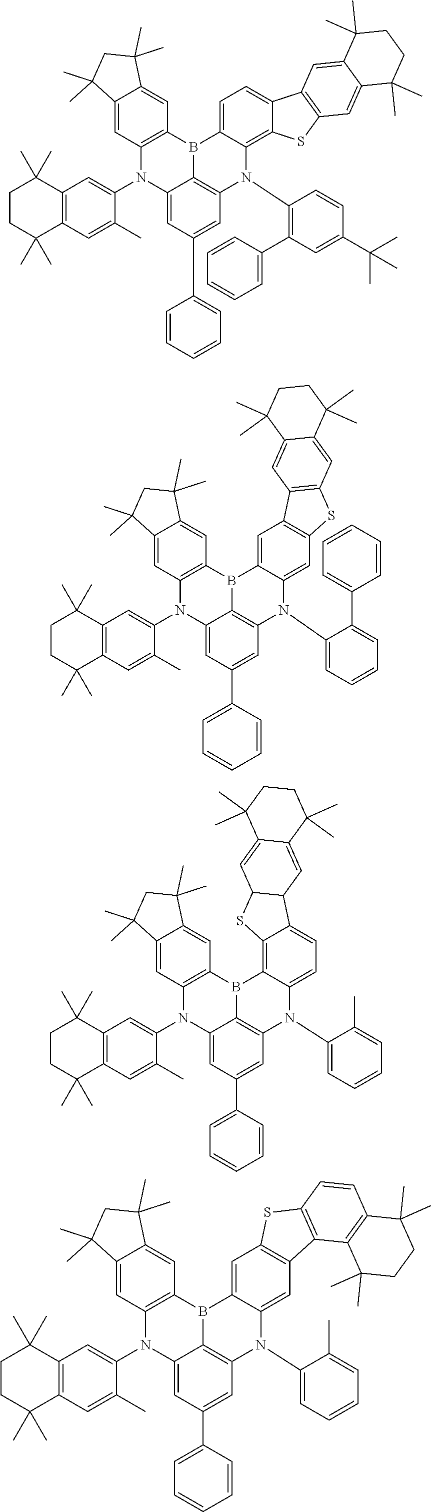

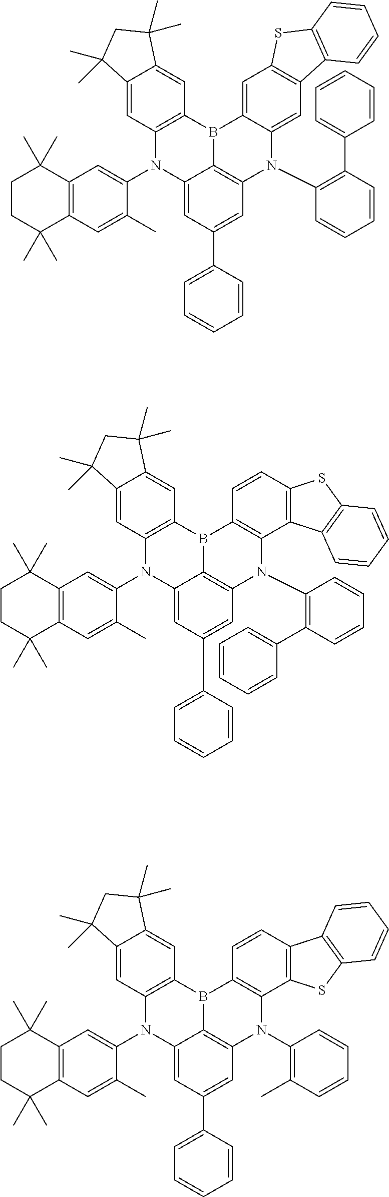 [SMILES: Cc1cc2c(cc1N1c3cc4c(cc3B3c5cc6sc7ccccc7c6cc5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5C)c5cc(-c6ccccc6)cc1c53)C(C)(C)CC4(C)C)C(C)(C)CCC2(C)C]

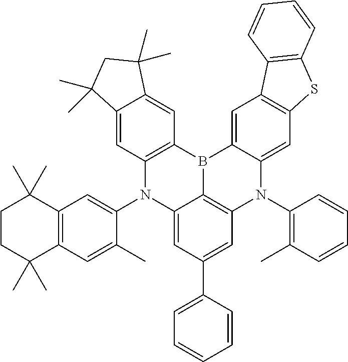 [SMILES: Cc1ccccc1N1c2cc3sc4ccccc4c3cc2B2c3cc4c(cc3N(c3cc5c(cc3C)C(C)(C)CCC5(C)C)c3cc(-c5ccccc5)cc1c32)C(C)(C)CC4(C)C]

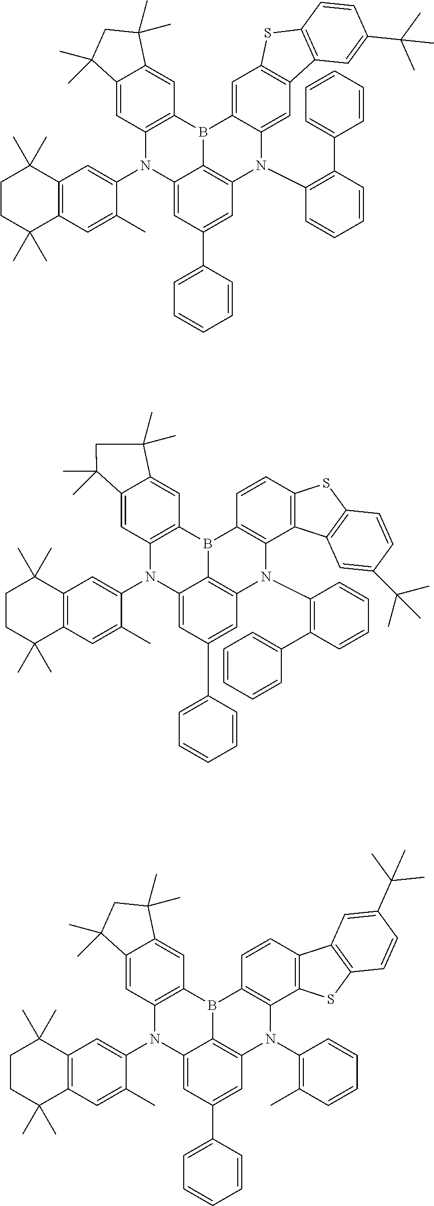 [SMILES: Cc1cc2c(cc1N1c3cc4c(cc3B3c5cc6sc7ccc(C(C)(C)C)cc7c6cc5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5ccccc5-c5ccccc5)c5cc(-c6ccccc6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(-c6ccccc6)cc1c53)C(C)(C)CC4(C)C)C(C)(C)CCC2(C)C]

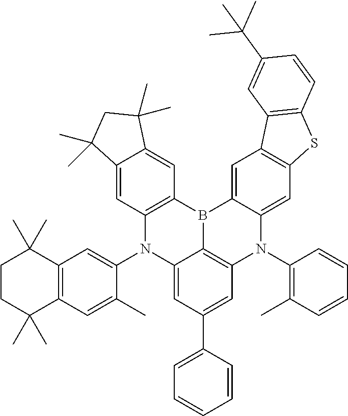 [SMILES: Cc1ccccc1N1c2cc3sc4ccc(C(C)(C)C)cc4c3cc2B2c3cc4c(cc3N(c3cc5c(cc3C)C(C)(C)CCC5(C)C)c3cc(-c5ccccc5)cc1c32)C(C)(C)CC4(C)C]

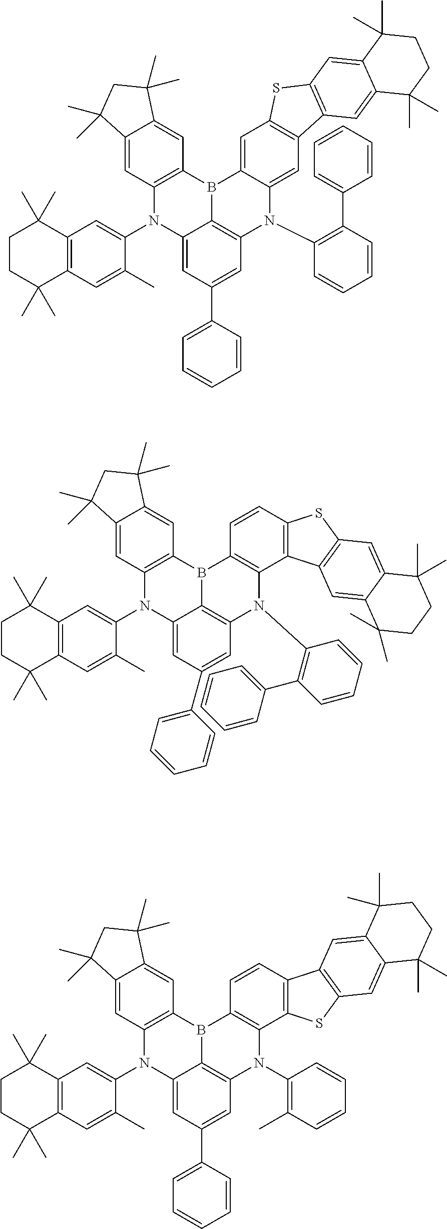 [SMILES: Cc1cc2c(cc1N1c3cc4c(cc3B3c5cc6sc7cc8c(cc7c6cc5N(c5ccccc5-c5ccccc5)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(-c6ccccc6)cc1c53)C(C)(C)CC4(C)C)C(C)(C)CCC2(C)C]

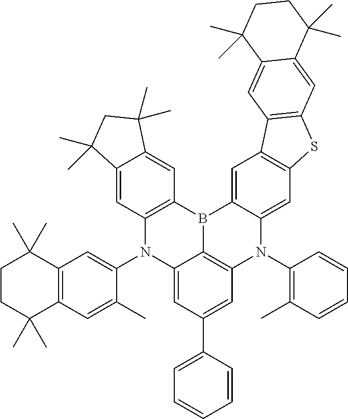 [SMILES: Cc1ccccc1N1c2cc3sc4cc5c(cc4c3cc2B2c3cc4c(cc3N(c3cc6c(cc3C)C(C)(C)CCC6(C)C)c3cc(-c6ccccc6)cc1c32)C(C)(C)CC4(C)C)C(C)(C)CCC5(C)C]

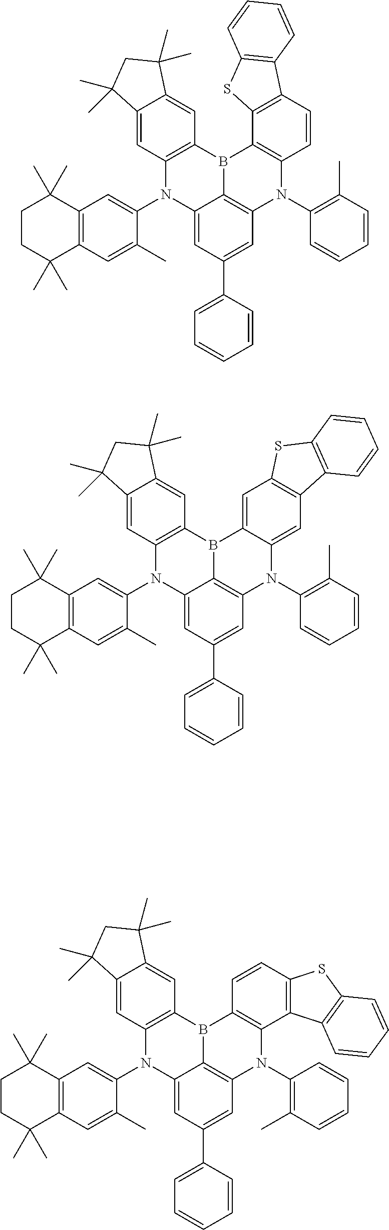 [SMILES: Cc1cc2c(cc1N1c3cc4c(cc3B3c5c1cc(-c1ccccc1)cc5N(c1ccccc1C)c1ccc5c(sc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)sc1ccccc13 ; Cc1cc2c(cc1N1c3cc4c(cc3B3c5ccc6sc7ccccc7c6c5N(c5ccccc5C)c5cc(-c6ccccc6)cc1c53)C(C)(C)CC4(C)C)C(C)(C)CCC2(C)C]

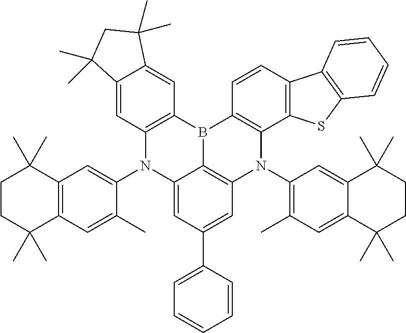 [SMILES: Cc1cc2c(cc1N1c3cc4c(cc3B3c5ccc6c(sc7ccccc76)c5N(c5cc6c(cc5C)C(C)(C)CCC6(C)C)c5cc(-c6ccccc6)cc1c53)C(C)(C)CC4(C)C)C(C)(C)CCC2(C)C]

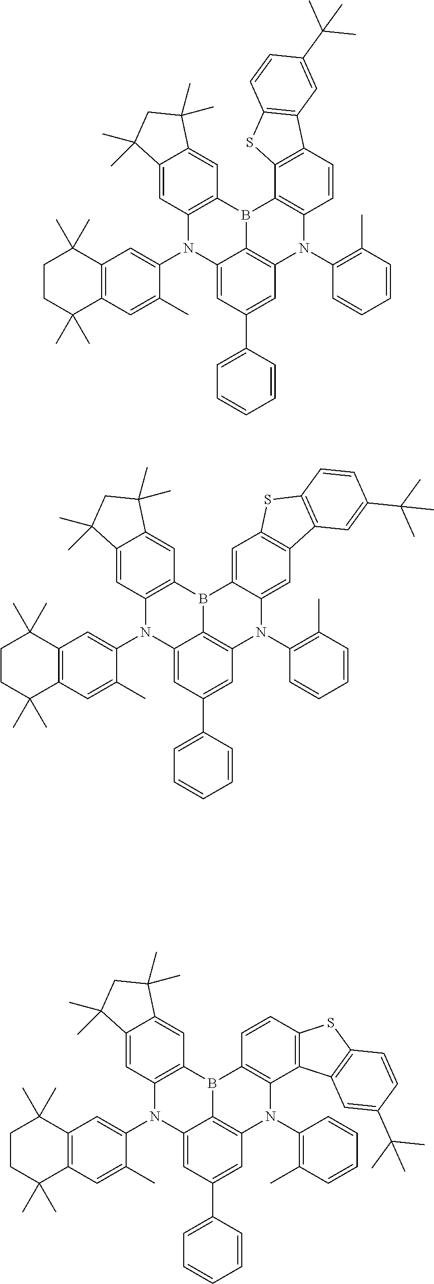 [SMILES: Cc1cc2c(cc1N1c3cc4c(cc3B3c5c1cc(-c1ccccc1)cc5N(c1ccccc1C)c1ccc5c(sc6ccc(C(C)(C)C)cc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)sc1ccc(C(C)(C)C)cc13 ; Cc1cc2c(cc1N1c3cc4c(cc3B3c5ccc6sc7ccc(C(C)(C)C)cc7c6c5N(c5ccccc5C)c5cc(-c6ccccc6)cc1c53)C(C)(C)CC4(C)C)C(C)(C)CCC2(C)C]

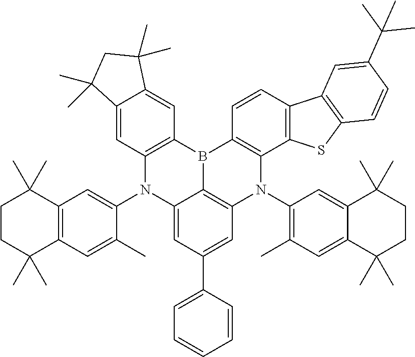 [SMILES: Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6ccccc6)cc1c53)C(C)(C)CC4(C)C)C(C)(C)CCC2(C)C]

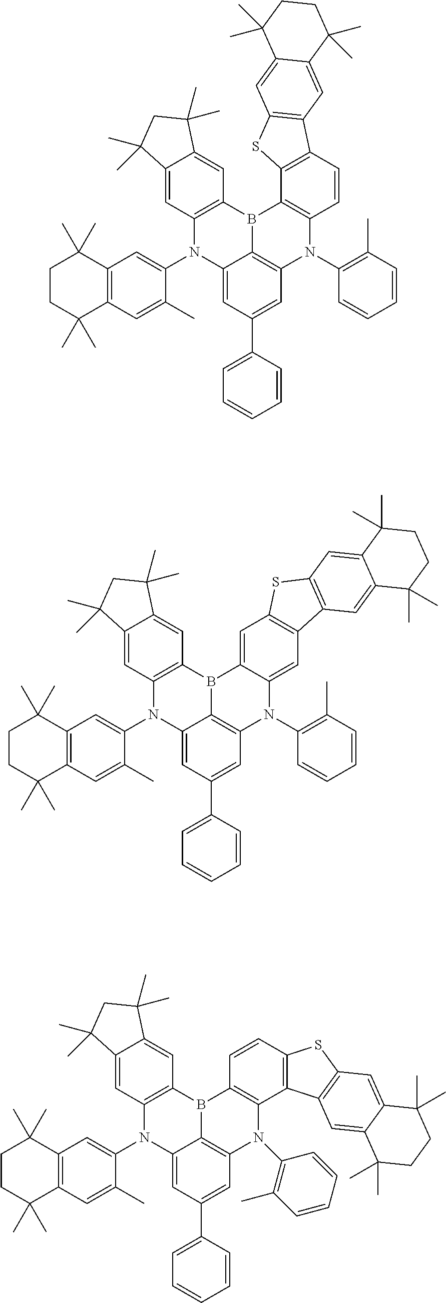 [SMILES: Cc1cc2c(cc1N1c3cc4c(cc3B3c5c1cc(-c1ccccc1)cc5N(c1ccccc1C)c1ccc5c(sc6cc7c(cc65)C(C)(C)CCC7(C)C)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(-c6ccccc6)cc1c53)C(C)(C)CCC8(C)C)C(C)(C)CC4(C)C)C(C)(C)CCC2(C)C]

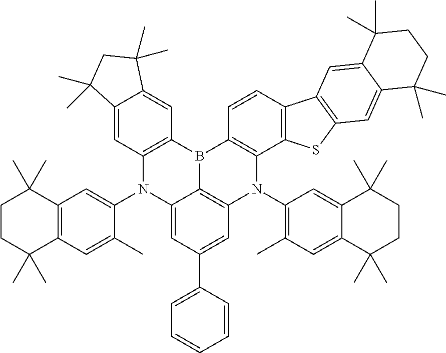 [SMILES: Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(-c6ccccc6)cc1c53)C(C)(C)CC4(C)C)C(C)(C)CCC2(C)C]

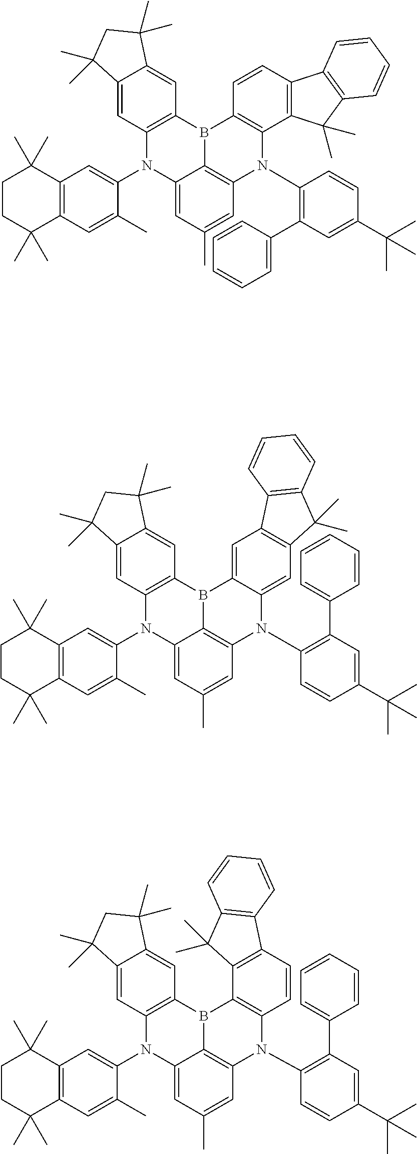 [SMILES: Cc1cc2c3c(c1)N(c1ccc(C(C)(C)C)cc1-c1ccccc1)c1c(ccc4c1C(C)(C)c1ccccc1-4)B3c1cc3c(cc1N2c1cc2c(cc1C)C(C)(C)CCC2(C)C)C(C)(C)CC3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1ccccc1C4(C)C ; Cc1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1ccccc1-4]

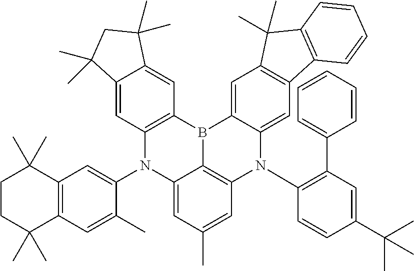 [SMILES: Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1ccccc1-4]

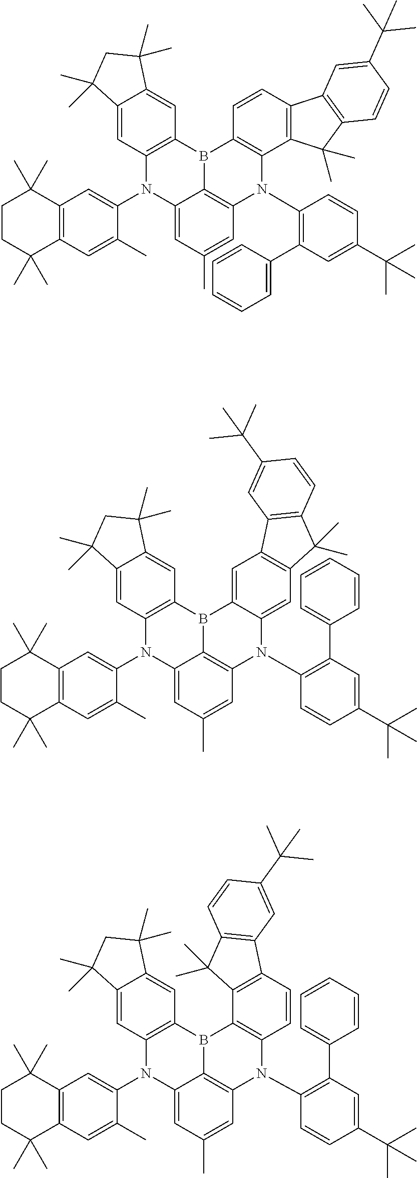 [SMILES: Cc1cc2c3c(c1)N(c1ccc(C(C)(C)C)cc1-c1ccccc1)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C ; Cc1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4]

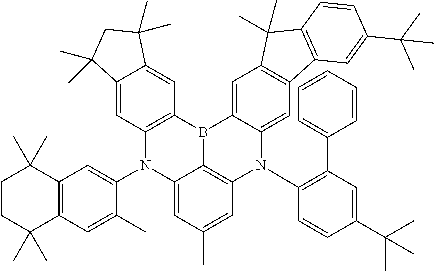 [SMILES: Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1ccc(C(C)(C)C)cc1-4]

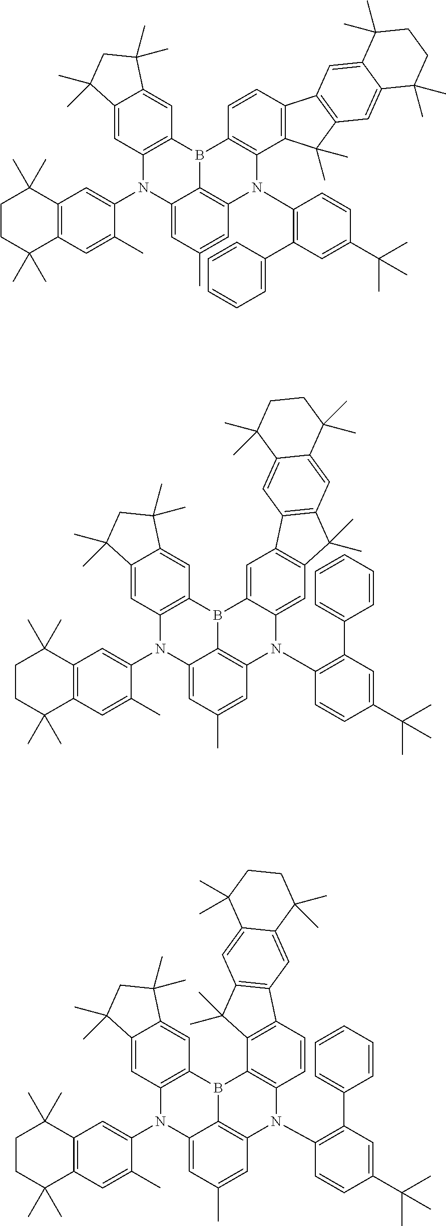 [SMILES: Cc1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

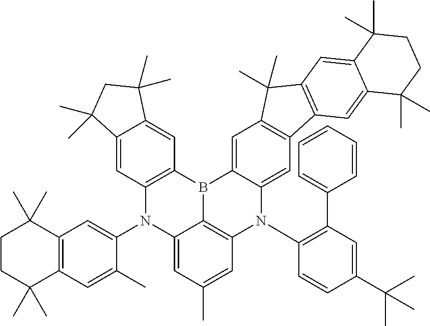 [SMILES: Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

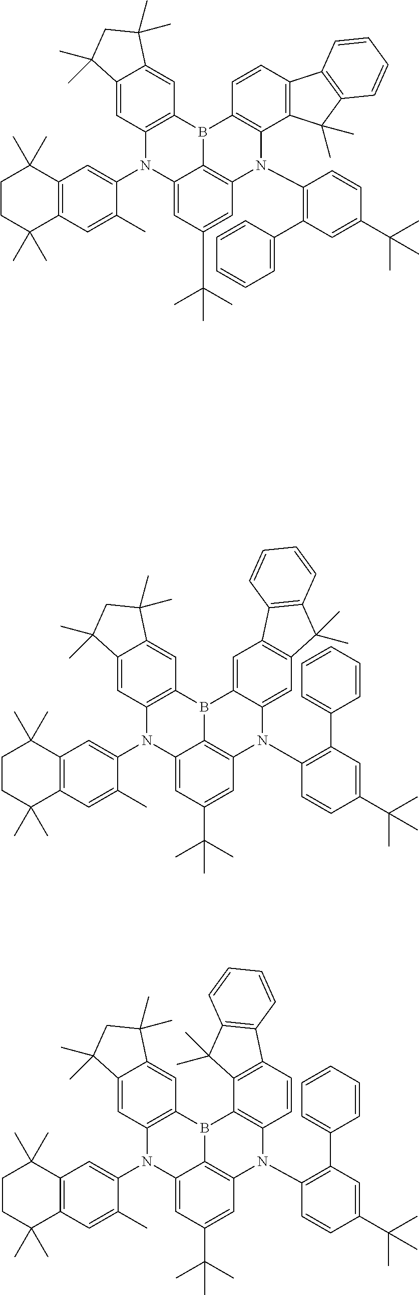 [SMILES: Cc1cc2c(cc1N1c3cc4c(cc3B3c5ccc6c(c5N(c5ccc(C(C)(C)C)cc5-c5ccccc5)c5cc(C(C)(C)C)cc1c53)C(C)(C)c1ccccc1-6)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)C(C)(C)c1ccccc1-6)C(C)(C)CC4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(c13)C(C)(C)c1ccccc1-5)C(C)(C)CC4(C)C)C(C)(C)CCC2(C)C]

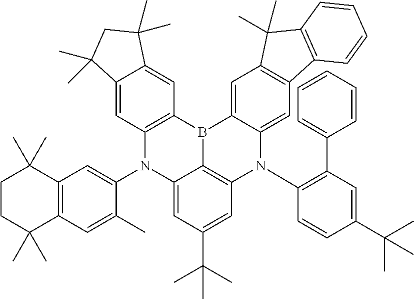 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)-c1ccccc1C6(C)C)C(C)(C)CC4(C)C)C(C)(C)CCC2(C)C]

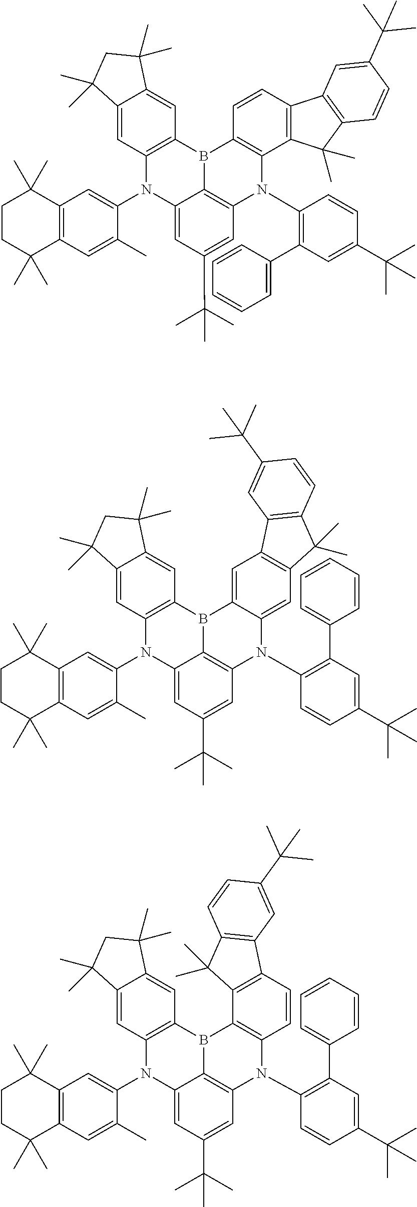 [SMILES: Cc1cc2c(cc1N1c3cc4c(cc3B3c5ccc6c(c5N(c5ccc(C(C)(C)C)cc5-c5ccccc5)c5cc(C(C)(C)C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C(C)(C)C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(C(C)(C)C)cc5N(c1ccc(C(C)(C)C)cc1-c1ccccc1)c1ccc5c(c13)C(C)(C)c1ccc(C(C)(C)C)cc1-5)C(C)(C)CC4(C)C)C(C)(C)CCC2(C)C]

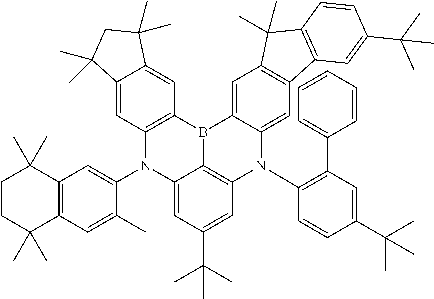 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)-c1cc(C(C)(C)C)ccc1C6(C)C)C(C)(C)CC4(C)C)C(C)(C)CCC2(C)C]

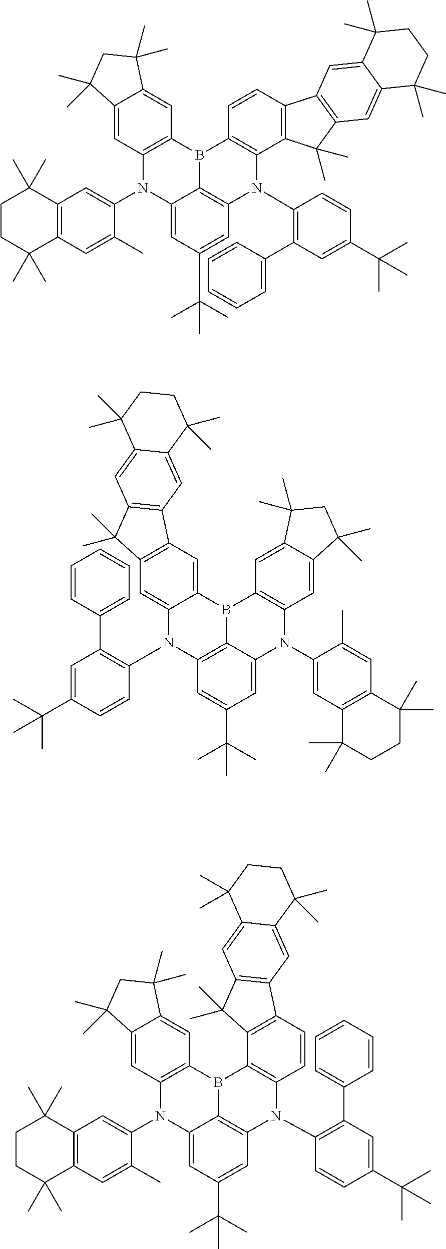

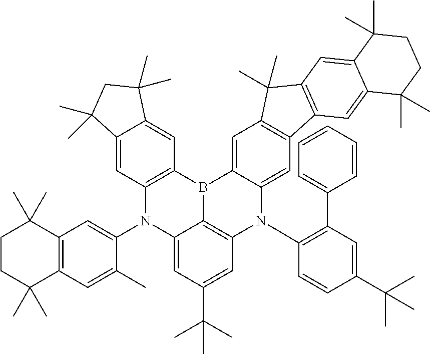 [SMILES: Cc1cc2c(cc1N1c3cc4c(cc3B3c5cc6c(cc5N(c5ccc(C(C)(C)C)cc5-c5ccccc5)c5cc(C(C)(C)C)cc1c53)-c1cc3c(cc1C6(C)C)C(C)(C)CCC3(C)C)C(C)(C)CC4(C)C)C(C)(C)CCC2(C)C]

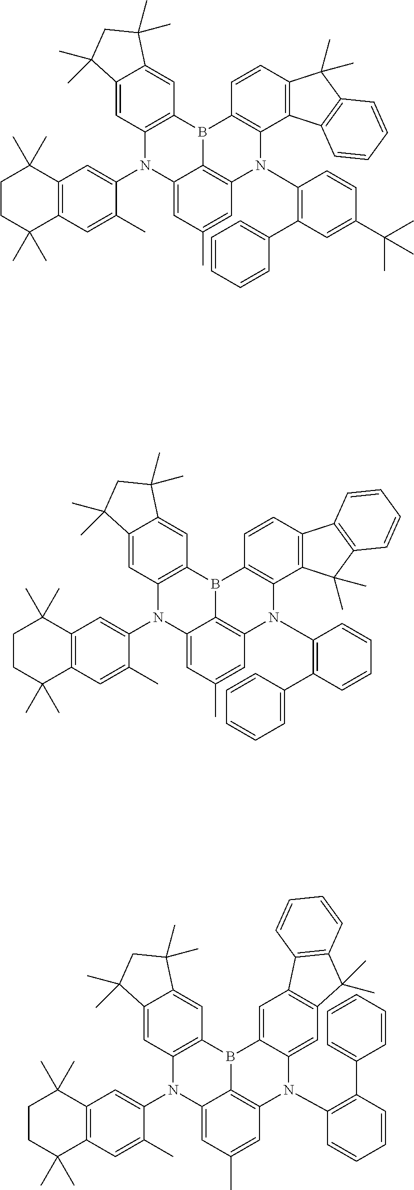 [SMILES: Cc1cc2c3c(c1)N(c1ccc(C(C)(C)C)cc1-c1ccccc1)c1c(ccc4c1-c1ccccc1C4(C)C)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1c(ccc4c1C(C)(C)c1ccccc1-4)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)-c1ccccc1C4(C)C]

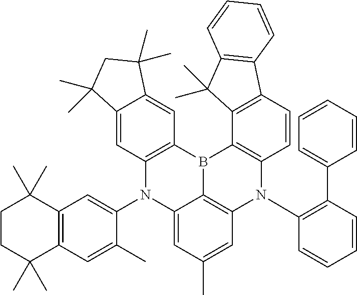 [SMILES: Cc1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1ccccc1-4]

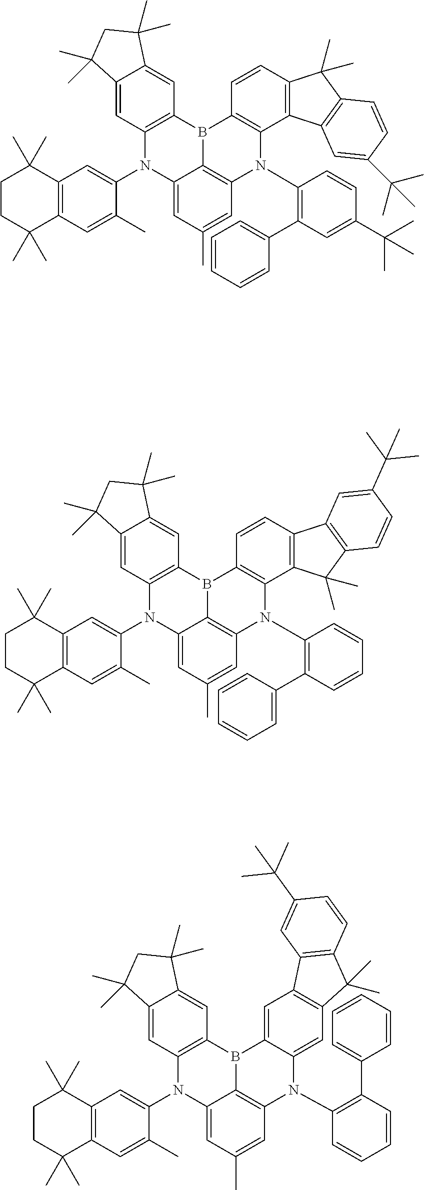 [SMILES: Cc1cc2c3c(c1)N(c1ccc(C(C)(C)C)cc1-c1ccccc1)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C]

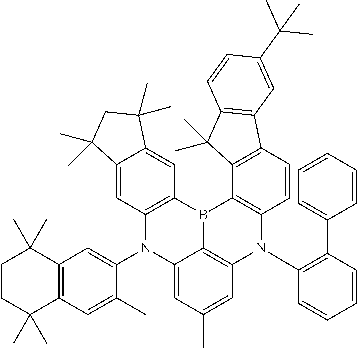 [SMILES: Cc1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4]

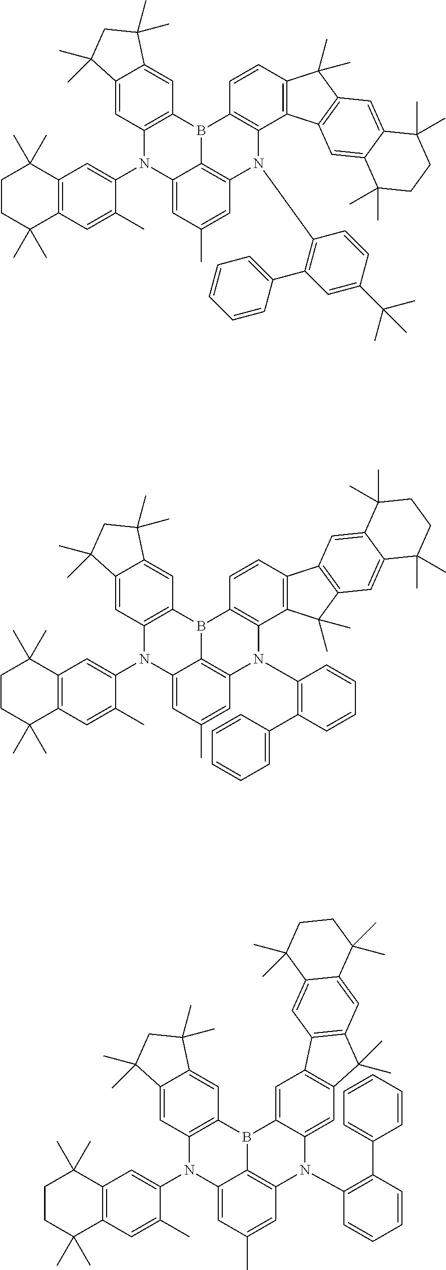 [SMILES: Cc1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C ; Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C]

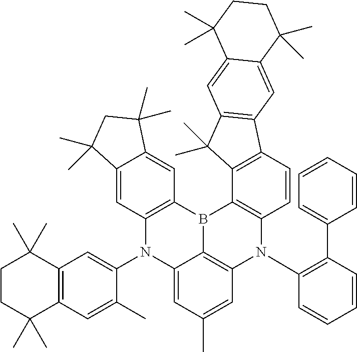 [SMILES: Cc1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

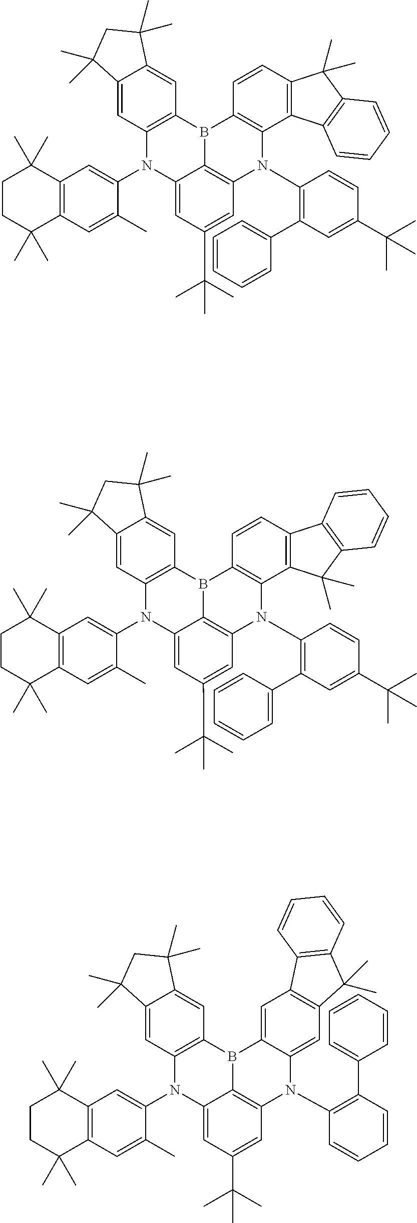 [SMILES: Cc1cc2c(cc1N1c3cc4c(cc3B3c5ccc6c(c5N(c5ccc(C(C)(C)C)cc5-c5ccccc5)c5cc(C(C)(C)C)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(C(C)(C)C)cc1c53)C(C)(C)c1ccccc1-6)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)C(C)(C)c1ccccc1-6)C(C)(C)CC4(C)C)C(C)(C)CCC2(C)C]

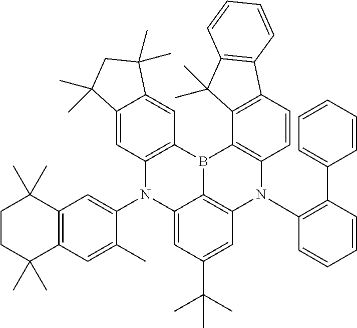 [SMILES: Cc1cc2c(cc1N1c3cc4c(cc3B3c5c1cc(C(C)(C)C)cc5N(c1ccccc1-c1ccccc1)c1ccc5c(c13)C(C)(C)c1ccccc1-5)C(C)(C)CC4(C)C)C(C)(C)CCC2(C)C]

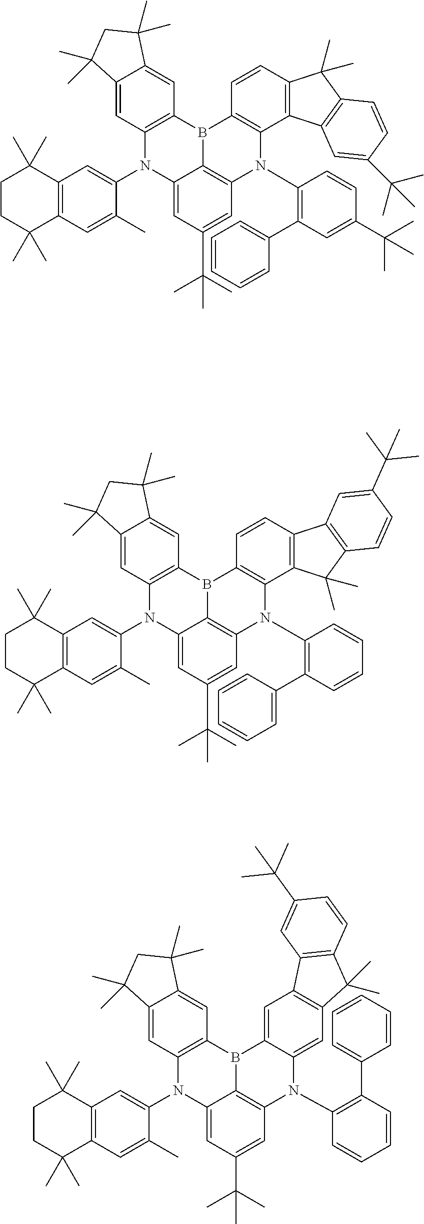 [SMILES: Cc1cc2c(cc1N1c3cc4c(cc3B3c5ccc6c(c5N(c5ccc(C(C)(C)C)cc5-c5ccccc5)c5cc(C(C)(C)C)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)C(C)(C)c1ccc(C(C)(C)C)cc1-6)C(C)(C)CC4(C)C)C(C)(C)CCC2(C)C]

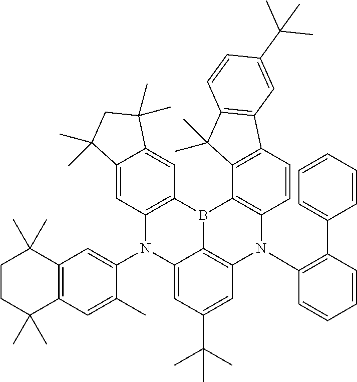 [SMILES: Cc1cc2c(cc1N1c3cc4c(cc3B3c5c1cc(C(C)(C)C)cc5N(c1ccccc1-c1ccccc1)c1ccc5c(c13)C(C)(C)c1ccc(C(C)(C)C)cc1-5)C(C)(C)CC4(C)C)C(C)(C)CCC2(C)C]

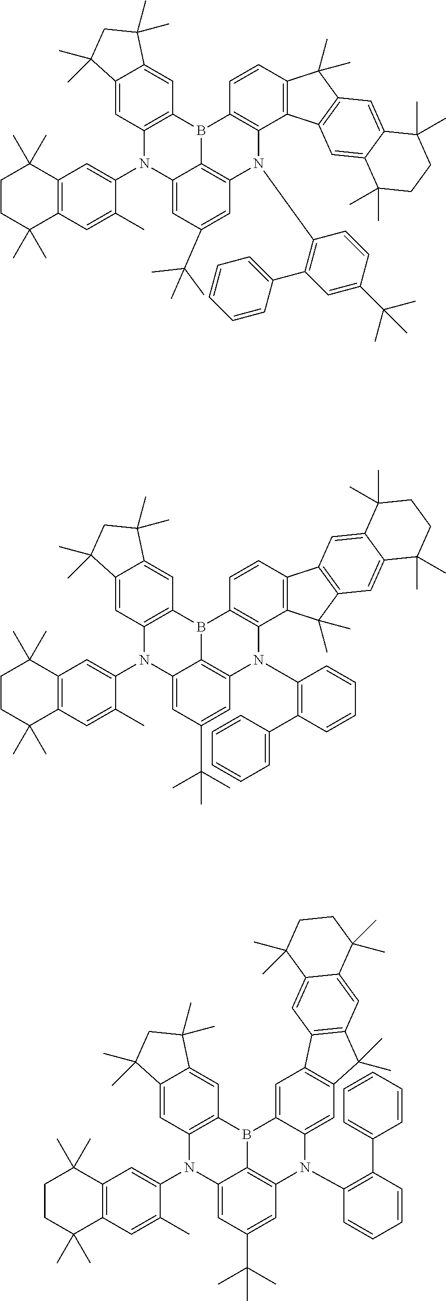 [SMILES: Cc1cc2c(cc1N1c3cc4c(cc3B3c5ccc6c(c5N(c5ccc(C(C)(C)C)cc5-c5ccccc5)c5cc(C(C)(C)C)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C(C)(C)C)cc1c53)C(C)(C)c1cc3c(cc1-6)C(C)(C)CCC3(C)C)C(C)(C)CC4(C)C)C(C)(C)CCC2(C)C]

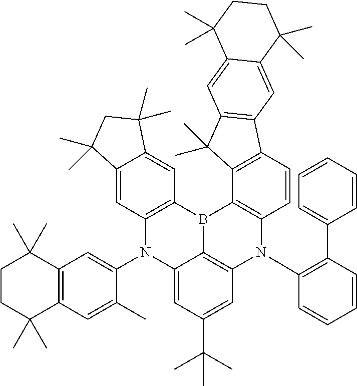 [SMILES: Cc1cc2c(cc1N1c3cc4c(cc3B3c5c1cc(C(C)(C)C)cc5N(c1ccccc1-c1ccccc1)c1ccc5c(c13)C(C)(C)c1cc3c(cc1-5)C(C)(C)CCC3(C)C)C(C)(C)CC4(C)C)C(C)(C)CCC2(C)C]

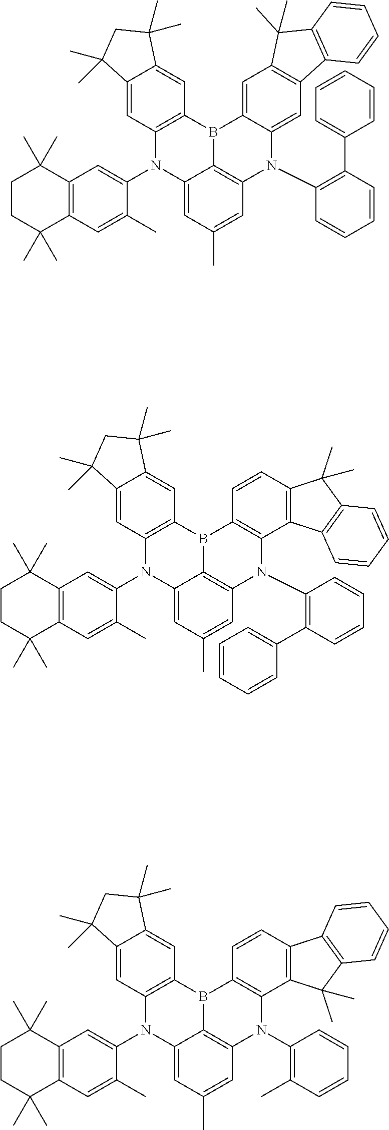 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)C(C)(C)c1ccccc1-4 ; Cc1cc2c3c(c1)N(c1ccccc1-c1ccccc1)c1c(ccc4c1-c1ccccc1C4(C)C)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1C(C)(C)c1ccccc1-4)B3c1cc3c(cc1N2c1cc2c(cc1C)C(C)(C)CCC2(C)C)C(C)(C)CC3(C)C]

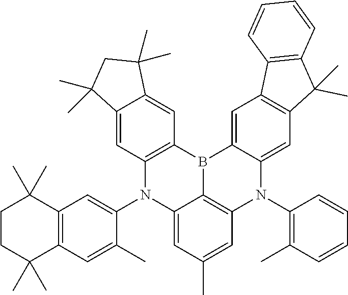 [SMILES: Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)-c1ccccc1C4(C)C]

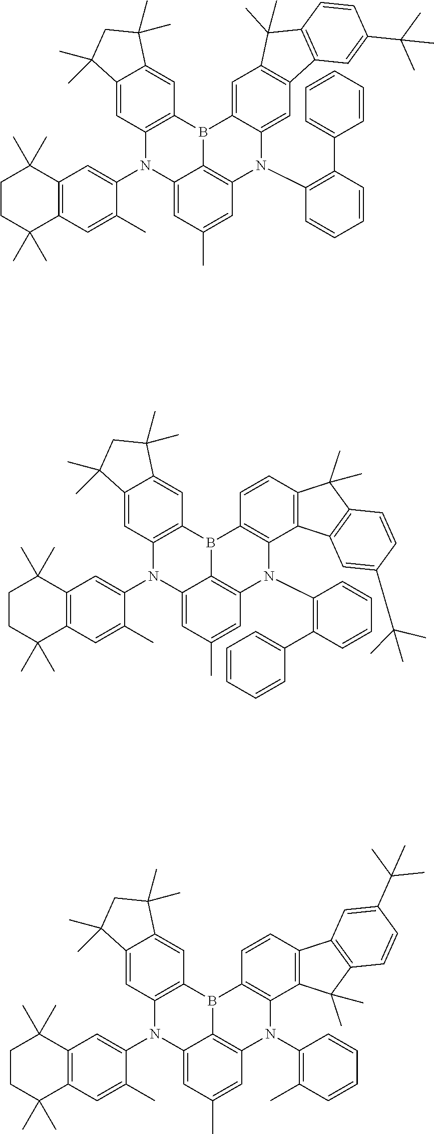 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1cc2c3c(c1)N(c1ccccc1-c1ccccc1)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C]

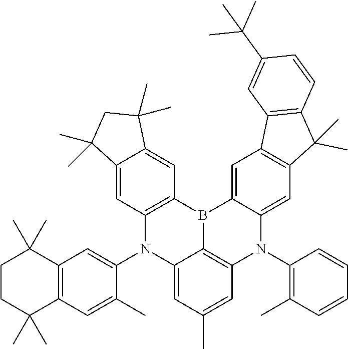 [SMILES: Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C]

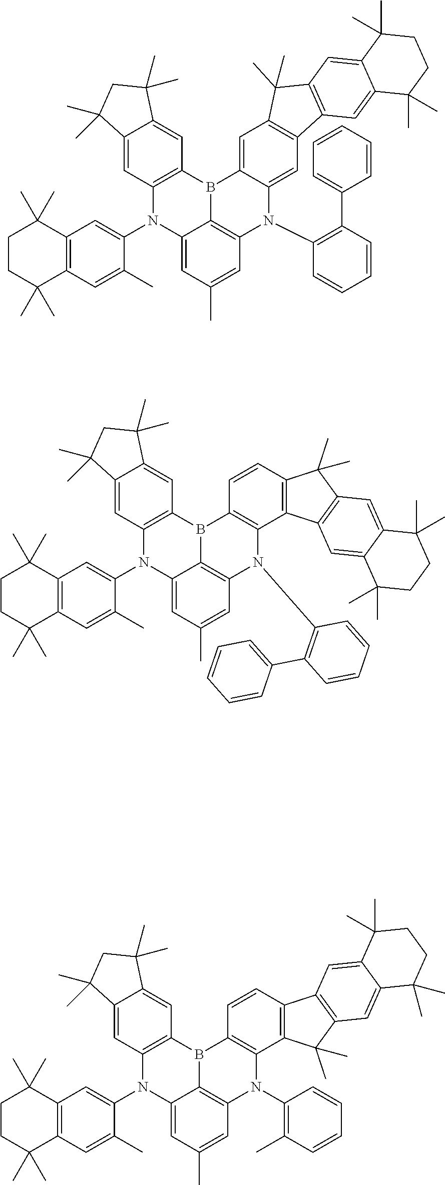 [SMILES: Cc1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1cc2c3c(c1)N(c1ccccc1-c1ccccc1)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C ; Cc1cc2c3c(c1)N(c1ccccc1C)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C]

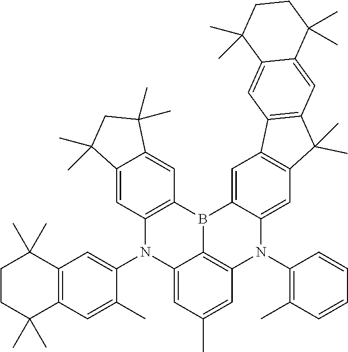 [SMILES: Cc1cc2c3c(c1)N(c1ccccc1C)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C]

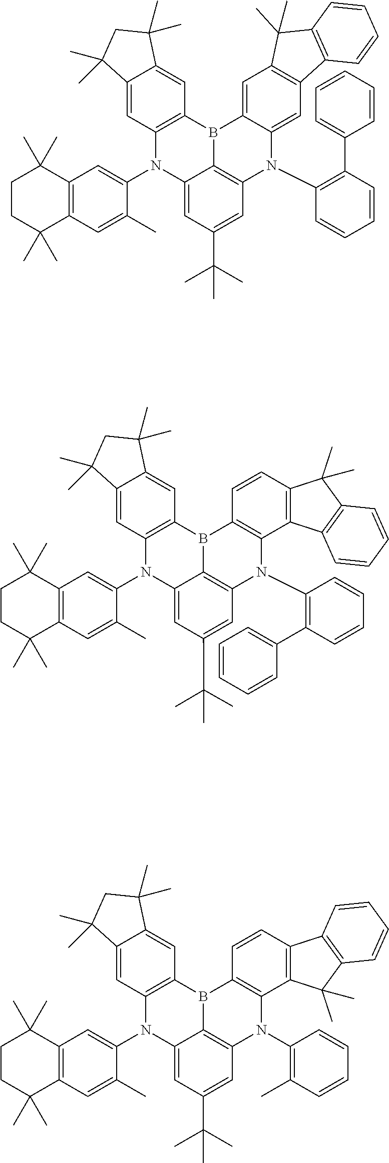 [SMILES: Cc1cc2c(cc1N1c3cc4c(cc3B3c5cc6c(cc5N(c5ccccc5-c5ccccc5)c5cc(C(C)(C)C)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5C)c5cc(C(C)(C)C)cc1c53)C(C)(C)c1ccccc1-6)C(C)(C)CC4(C)C)C(C)(C)CCC2(C)C]

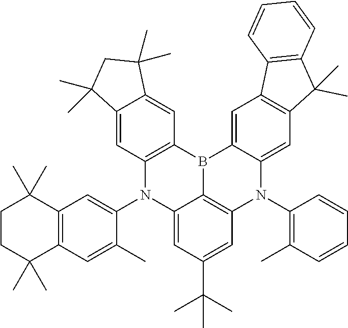 [SMILES: Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)-c1ccccc1C3(C)C]

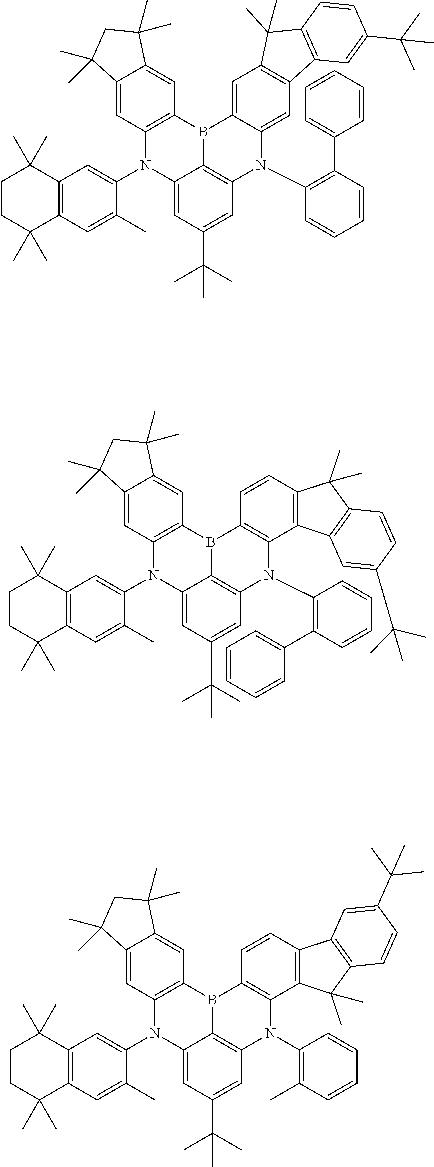 [SMILES: Cc1cc2c(cc1N1c3cc4c(cc3B3c5cc6c(cc5N(c5ccccc5-c5ccccc5)c5cc(C(C)(C)C)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5C)c5cc(C(C)(C)C)cc1c53)C(C)(C)c1ccc(C(C)(C)C)cc1-6)C(C)(C)CC4(C)C)C(C)(C)CCC2(C)C]

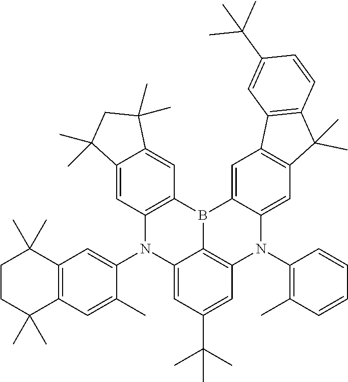 [SMILES: Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)-c1cc(C(C)(C)C)ccc1C3(C)C]

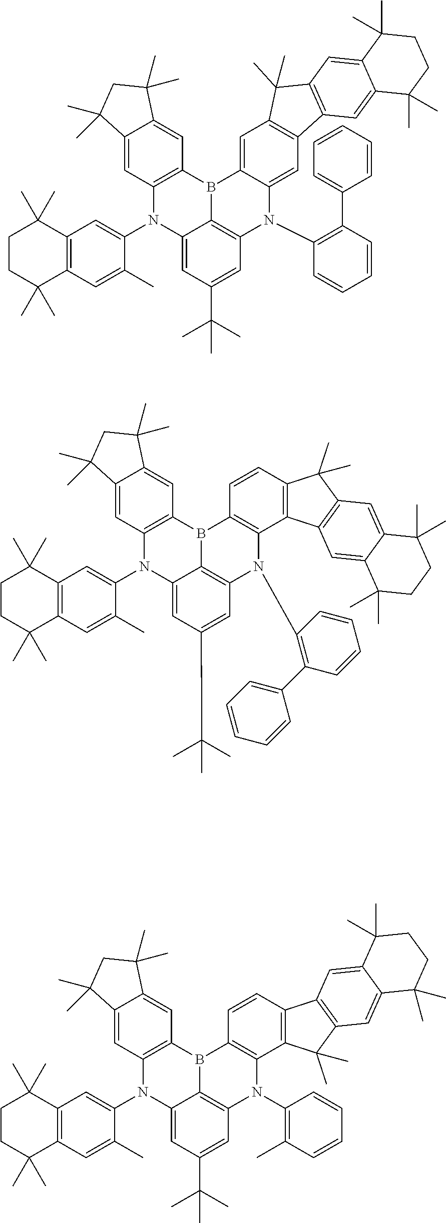 [SMILES: Cc1cc2c(cc1N1c3cc4c(cc3B3c5cc6c(cc5N(c5ccccc5-c5ccccc5)c5cc(C(C)(C)C)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(C(C)(C)C)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5C)c5cc(C(C)(C)C)cc1c53)C(C)(C)c1cc3c(cc1-6)C(C)(C)CCC3(C)C)C(C)(C)CC4(C)C)C(C)(C)CCC2(C)C]

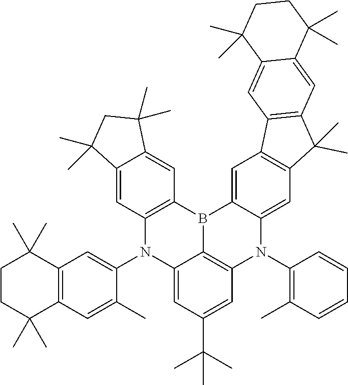 [SMILES: Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)-c1cc2c(cc1C3(C)C)C(C)(C)CCC2(C)C]

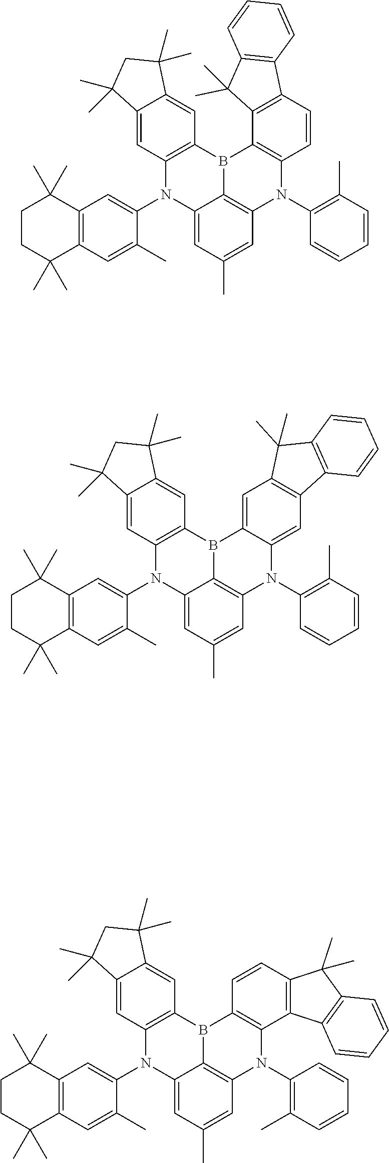 [SMILES: Cc1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1ccccc1-4 ; Cc1cc2c3c(c1)N(c1cc4c(cc1C)C(C)(C)CCC4(C)C)c1cc4c(cc1B3c1cc3c(cc1N2c1ccccc1C)-c1ccccc1C3(C)C)C(C)(C)CC4(C)C ; Cc1cc2c3c(c1)N(c1ccccc1C)c1c(ccc4c1-c1ccccc1C4(C)C)B3c1cc3c(cc1N2c1cc2c(cc1C)C(C)(C)CCC2(C)C)C(C)(C)CC3(C)C]

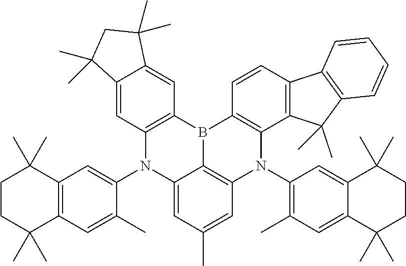 [SMILES: Cc1cc2c3c(c1)N(c1cc4c(cc1C)C(C)(C)CCC4(C)C)c1c(ccc4c1C(C)(C)c1ccccc1-4)B3c1cc3c(cc1N2c1cc2c(cc1C)C(C)(C)CCC2(C)C)C(C)(C)CC3(C)C]

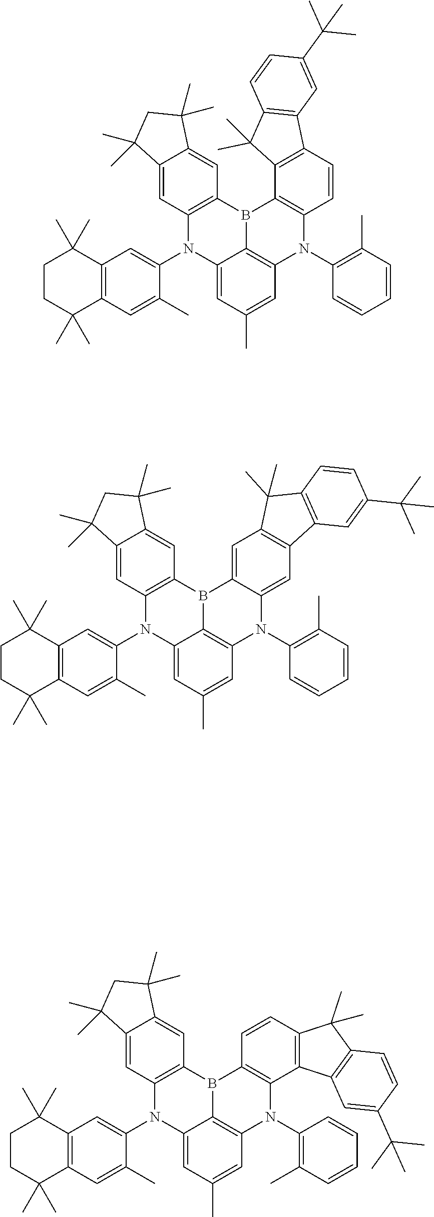 [SMILES: Cc1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1cc2c3c(c1)N(c1cc4c(cc1C)C(C)(C)CCC4(C)C)c1cc4c(cc1B3c1cc3c(cc1N2c1ccccc1C)-c1cc(C(C)(C)C)ccc1C3(C)C)C(C)(C)CC4(C)C ; Cc1cc2c3c(c1)N(c1ccccc1C)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C]

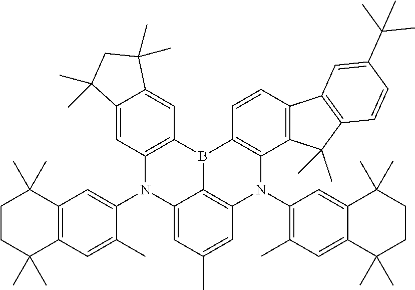 [SMILES: Cc1cc2c3c(c1)N(c1cc4c(cc1C)C(C)(C)CCC4(C)C)c1c(ccc4c1C(C)(C)c1ccc(C(C)(C)C)cc1-4)B3c1cc3c(cc1N2c1cc2c(cc1C)C(C)(C)CCC2(C)C)C(C)(C)CC3(C)C]

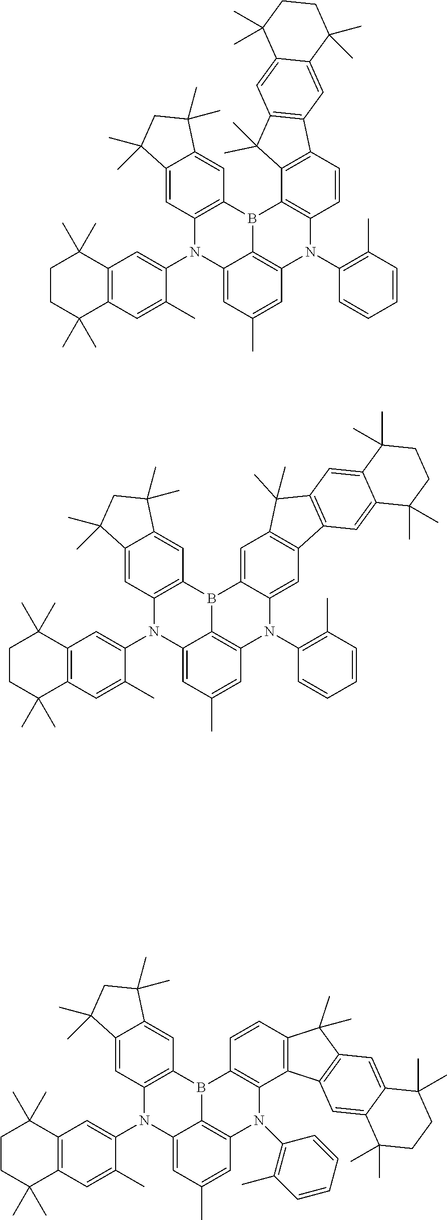 [SMILES: Cc1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1cc2c3c(c1)N(c1cc4c(cc1C)C(C)(C)CCC4(C)C)c1cc4c(cc1B3c1cc3c(cc1N2c1ccccc1C)-c1cc2c(cc1C3(C)C)C(C)(C)CCC2(C)C)C(C)(C)CC4(C)C ; Cc1cc2c3c(c1)N(c1ccccc1C)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C]

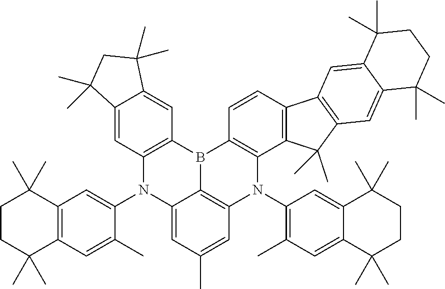 [SMILES: Cc1cc2c3c(c1)N(c1cc4c(cc1C)C(C)(C)CCC4(C)C)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C]

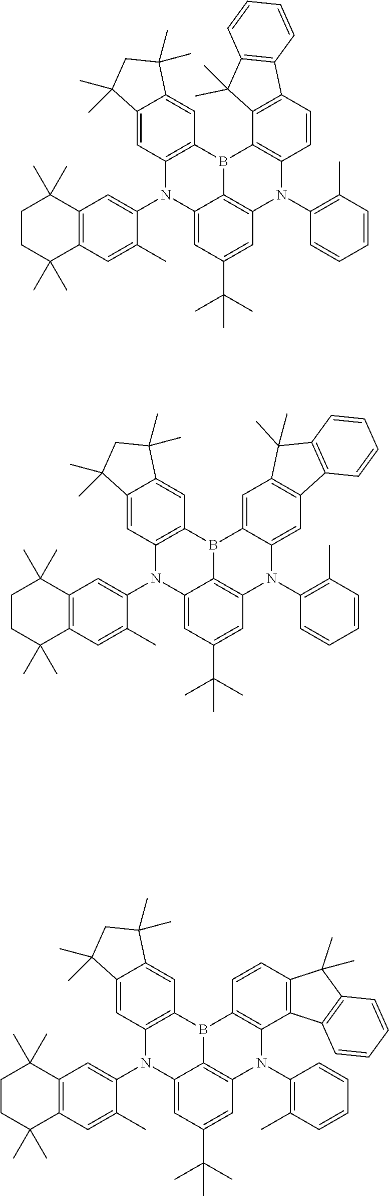 [SMILES: Cc1cc2c(cc1N1c3cc4c(cc3B3c5c1cc(C(C)(C)C)cc5N(c1ccccc1C)c1ccc5c(c13)C(C)(C)c1ccccc1-5)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)C(C)(C)c1ccccc1-3 ; Cc1cc2c(cc1N1c3cc4c(cc3B3c5ccc6c(c5N(c5ccccc5C)c5cc(C(C)(C)C)cc1c53)-c1ccccc1C6(C)C)C(C)(C)CC4(C)C)C(C)(C)CCC2(C)C]

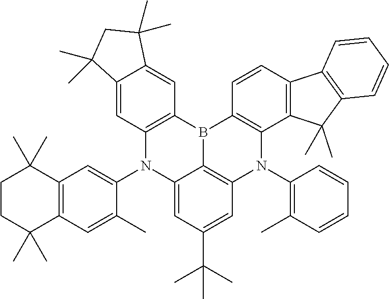 [SMILES: Cc1cc2c(cc1N1c3cc4c(cc3B3c5ccc6c(c5N(c5ccccc5C)c5cc(C(C)(C)C)cc1c53)C(C)(C)c1ccccc1-6)C(C)(C)CC4(C)C)C(C)(C)CCC2(C)C]

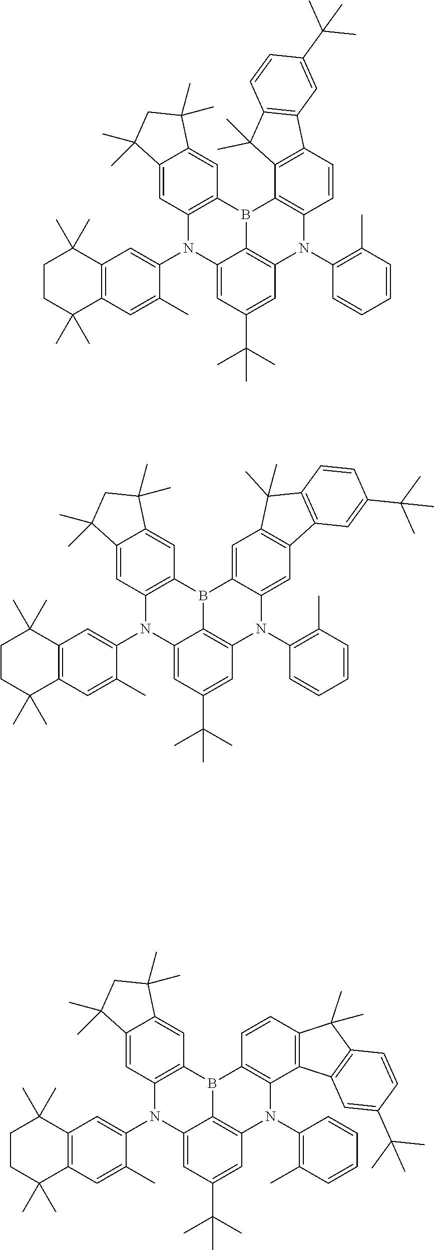 [SMILES: Cc1cc2c(cc1N1c3cc4c(cc3B3c5c1cc(C(C)(C)C)cc5N(c1ccccc1C)c1ccc5c(c13)C(C)(C)c1ccc(C(C)(C)C)cc1-5)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)C(C)(C)c1ccc(C(C)(C)C)cc1-3 ; Cc1cc2c(cc1N1c3cc4c(cc3B3c5ccc6c(c5N(c5ccccc5C)c5cc(C(C)(C)C)cc1c53)-c1cc(C(C)(C)C)ccc1C6(C)C)C(C)(C)CC4(C)C)C(C)(C)CCC2(C)C]

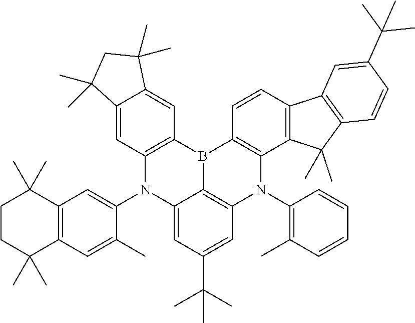 [SMILES: Cc1cc2c(cc1N1c3cc4c(cc3B3c5ccc6c(c5N(c5ccccc5C)c5cc(C(C)(C)C)cc1c53)C(C)(C)c1ccc(C(C)(C)C)cc1-6)C(C)(C)CC4(C)C)C(C)(C)CCC2(C)C]

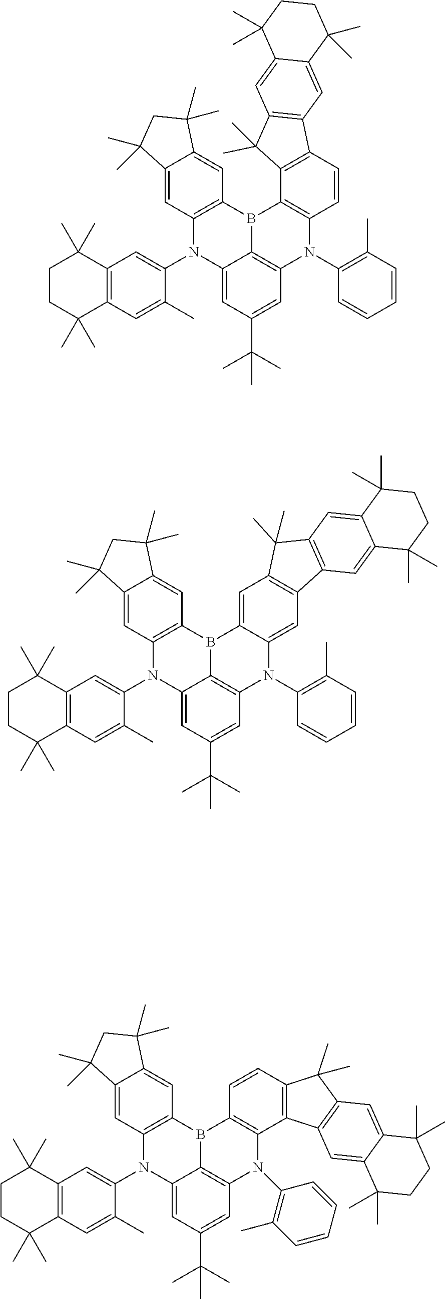 [SMILES: Cc1cc2c(cc1N1c3cc4c(cc3B3c5c1cc(C(C)(C)C)cc5N(c1ccccc1C)c1ccc5c(c13)C(C)(C)c1cc3c(cc1-5)C(C)(C)CCC3(C)C)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C(C)(C)C)cc1c42)C(C)(C)CC5(C)C)C(C)(C)c1cc2c(cc1-3)C(C)(C)CCC2(C)C ; Cc1cc2c(cc1N1c3cc4c(cc3B3c5ccc6c(c5N(c5ccccc5C)c5cc(C(C)(C)C)cc1c53)-c1cc3c(cc1C6(C)C)C(C)(C)CCC3(C)C)C(C)(C)CC4(C)C)C(C)(C)CCC2(C)C]

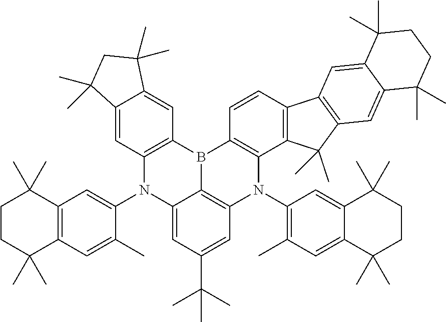 [SMILES: Cc1cc2c(cc1N1c3cc4c(cc3B3c5ccc6c(c5N(c5cc7c(cc5C)C(C)(C)CCC7(C)C)c5cc(C(C)(C)C)cc1c53)C(C)(C)c1cc3c(cc1-6)C(C)(C)CCC3(C)C)C(C)(C)CC4(C)C)C(C)(C)CCC2(C)C]

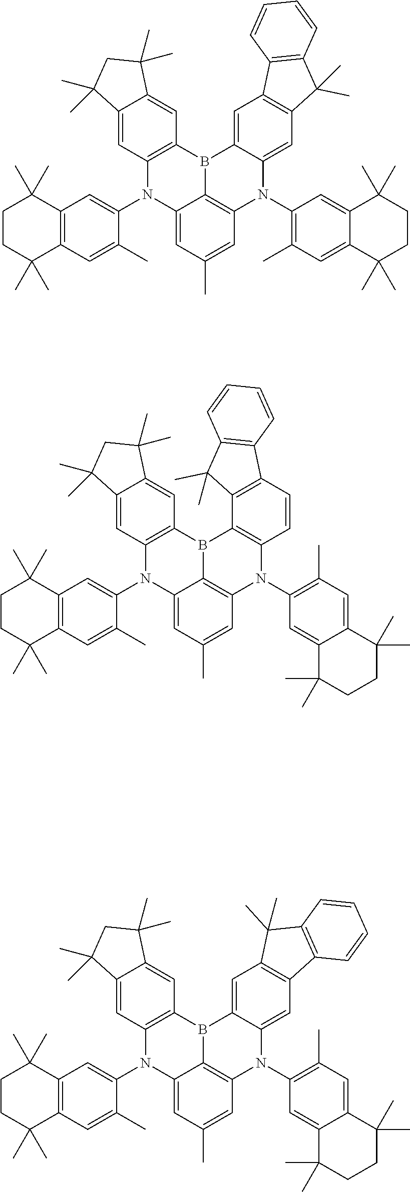 [SMILES: Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1ccccc1C4(C)C ; Cc1cc2c3c(c1)N(c1cc4c(cc1C)C(C)(C)CCC4(C)C)c1ccc4c(c1B3c1cc3c(cc1N2c1cc2c(cc1C)C(C)(C)CCC2(C)C)C(C)(C)CC3(C)C)C(C)(C)c1ccccc1-4 ; Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)-c1ccccc1C3(C)C)C(C)(C)CC4(C)C]

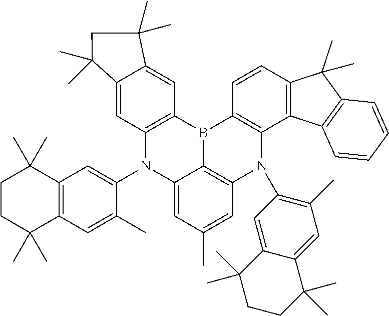 [SMILES: Cc1cc2c3c(c1)N(c1cc4c(cc1C)C(C)(C)CCC4(C)C)c1c(ccc4c1-c1ccccc1C4(C)C)B3c1cc3c(cc1N2c1cc2c(cc1C)C(C)(C)CCC2(C)C)C(C)(C)CC3(C)C]

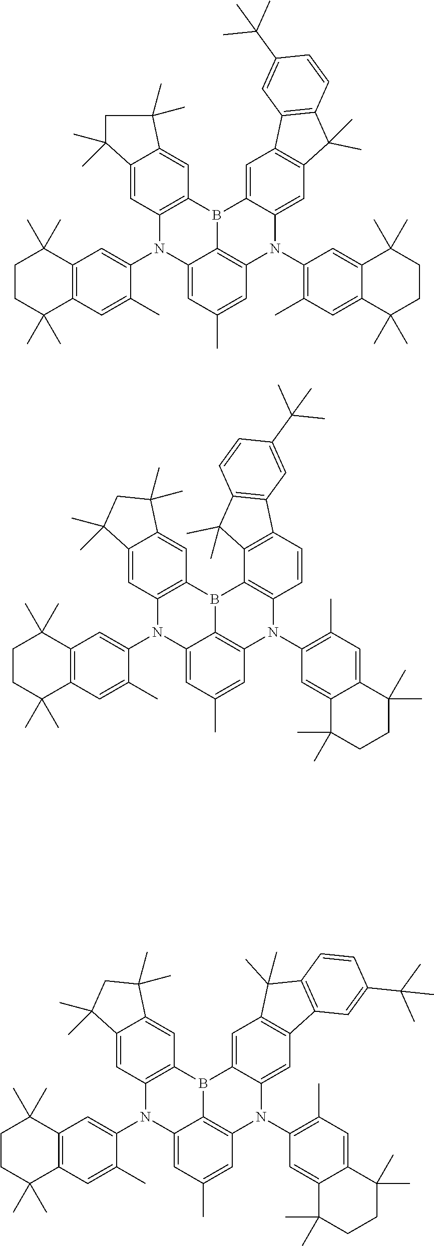 [SMILES: Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1cc(C(C)(C)C)ccc1C4(C)C ; Cc1cc2c3c(c1)N(c1cc4c(cc1C)C(C)(C)CCC4(C)C)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)-c1cc(C(C)(C)C)ccc1C3(C)C)C(C)(C)CC4(C)C]

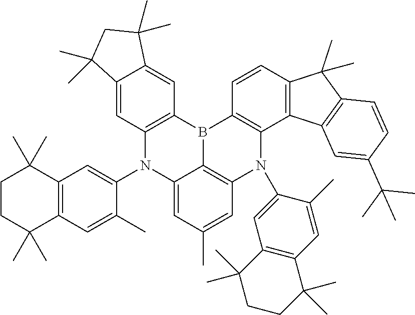 [SMILES: Cc1cc2c3c(c1)N(c1cc4c(cc1C)C(C)(C)CCC4(C)C)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C]

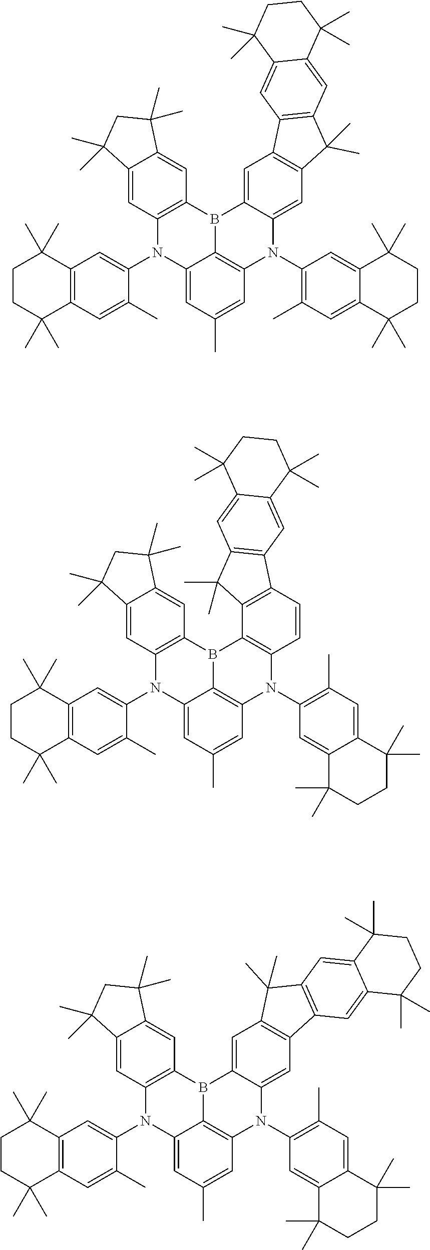 [SMILES: Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1cc2c3c(c1)N(c1cc4c(cc1C)C(C)(C)CCC4(C)C)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)-c1cc2c(cc1C3(C)C)C(C)(C)CCC2(C)C)C(C)(C)CC4(C)C]

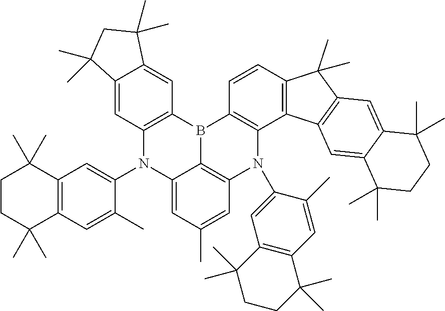 [SMILES: Cc1cc2c3c(c1)N(c1cc4c(cc1C)C(C)(C)CCC4(C)C)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C]

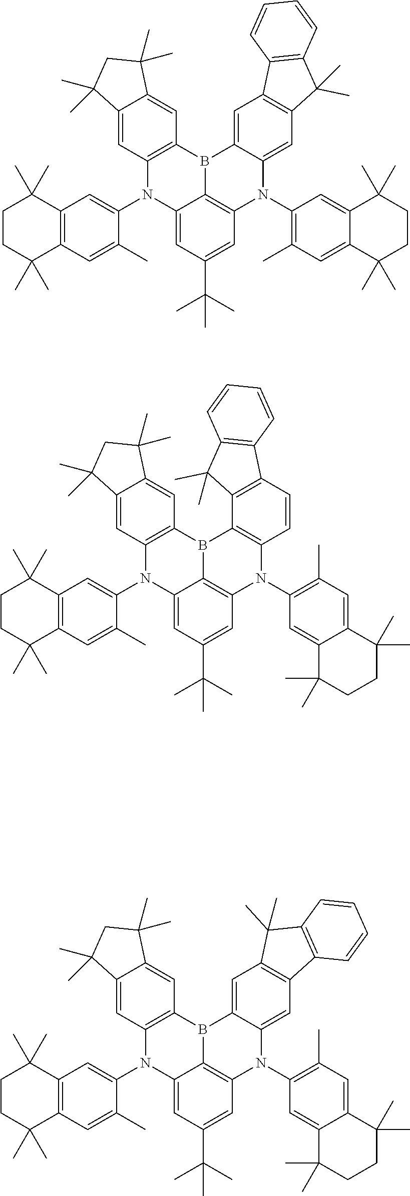 [SMILES: Cc1cc2c(cc1N1c3cc4c(cc3B3c5cc6c(cc5N(c5cc7c(cc5C)C(C)(C)CCC7(C)C)c5cc(C(C)(C)C)cc1c53)C(C)(C)c1ccccc1-6)C(C)(C)CC4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(c13)C(C)(C)c1ccccc1-5)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C(C)(C)C)cc1c53)C(C)(C)CC6(C)C)C(C)(C)c1ccccc1-4)C(C)(C)CCC2(C)C]

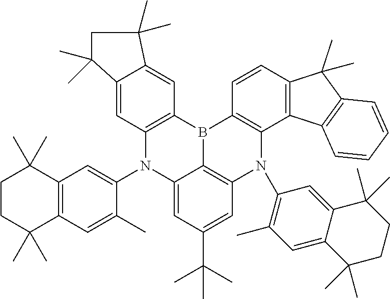 [SMILES: Cc1cc2c(cc1N1c3cc4c(cc3B3c5ccc6c(c5N(c5cc7c(cc5C)C(C)(C)CCC7(C)C)c5cc(C(C)(C)C)cc1c53)-c1ccccc1C6(C)C)C(C)(C)CC4(C)C)C(C)(C)CCC2(C)C]

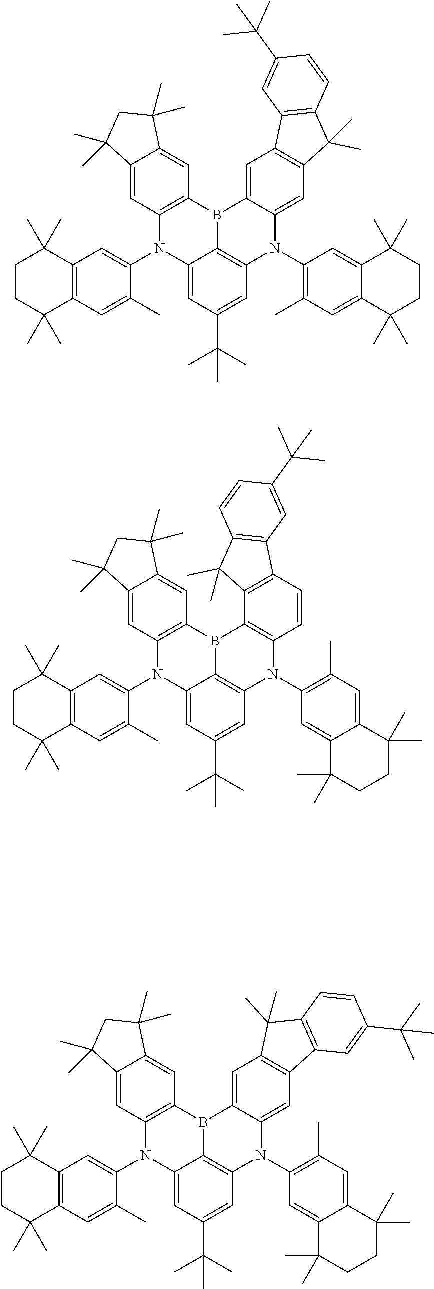 [SMILES: Cc1cc2c(cc1N1c3cc4c(cc3B3c5cc6c(cc5N(c5cc7c(cc5C)C(C)(C)CCC7(C)C)c5cc(C(C)(C)C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(c13)C(C)(C)c1ccc(C(C)(C)C)cc1-5)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C(C)(C)C)cc1c53)C(C)(C)CC6(C)C)C(C)(C)c1ccc(C(C)(C)C)cc1-4)C(C)(C)CCC2(C)C]

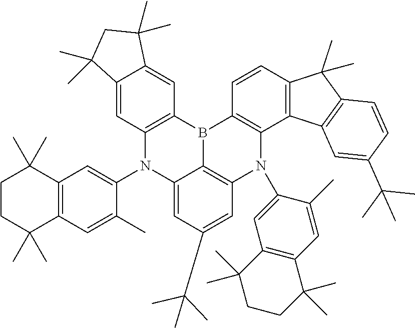 [SMILES: Cc1cc2c(cc1N1c3cc4c(cc3B3c5ccc6c(c5N(c5cc7c(cc5C)C(C)(C)CCC7(C)C)c5cc(C(C)(C)C)cc1c53)-c1cc(C(C)(C)C)ccc1C6(C)C)C(C)(C)CC4(C)C)C(C)(C)CCC2(C)C]

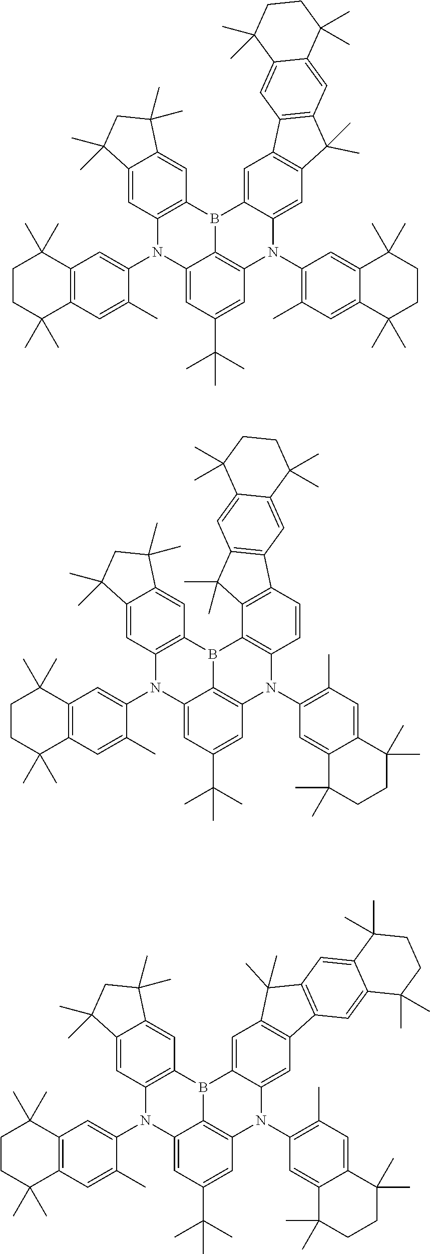 [SMILES: Cc1cc2c(cc1N1c3cc4c(cc3B3c5cc6c(cc5N(c5cc7c(cc5C)C(C)(C)CCC7(C)C)c5cc(C(C)(C)C)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5c1cc(C(C)(C)C)cc5N(c1cc5c(cc1C)C(C)(C)CCC5(C)C)c1ccc5c(c13)C(C)(C)c1cc3c(cc1-5)C(C)(C)CCC3(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C(C)(C)C)cc1c53)C(C)(C)CC6(C)C)C(C)(C)c1cc3c(cc1-4)C(C)(C)CCC3(C)C)C(C)(C)CCC2(C)C]

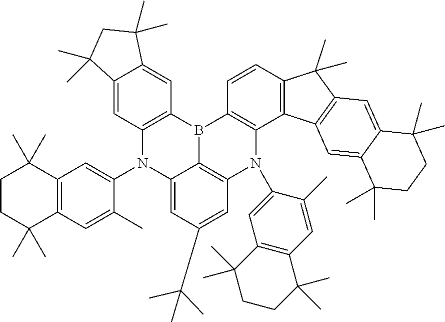 [SMILES: Cc1cc2c(cc1N1c3cc4c(cc3B3c5ccc6c(c5N(c5cc7c(cc5C)C(C)(C)CCC7(C)C)c5cc(C(C)(C)C)cc1c53)-c1cc3c(cc1C6(C)C)C(C)(C)CCC3(C)C)C(C)(C)CC4(C)C)C(C)(C)CCC2(C)C]

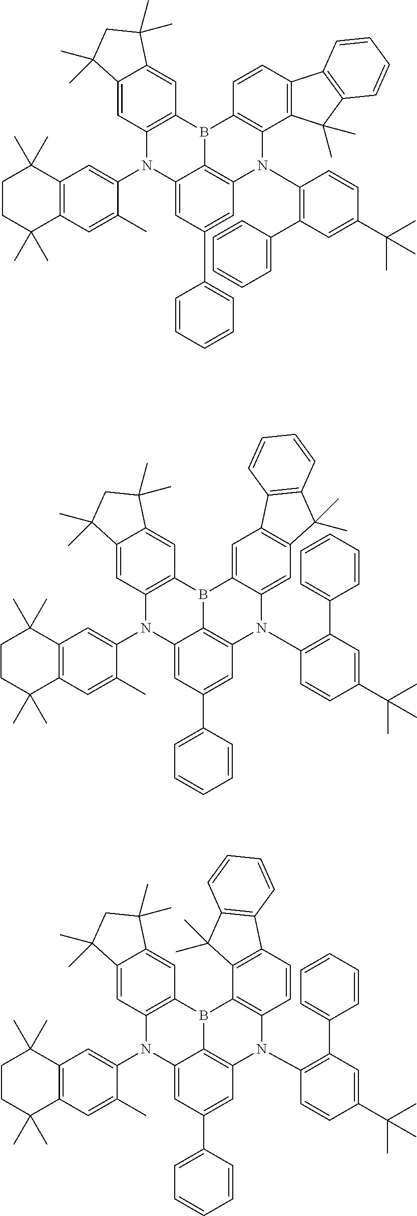 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)C(C)(C)c1ccccc1-6)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)C(C)(C)c1ccccc1-6)C(C)(C)CC4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(c13)C(C)(C)c1ccccc1-5)C(C)(C)CC4(C)C)C(C)(C)CCC2(C)C]

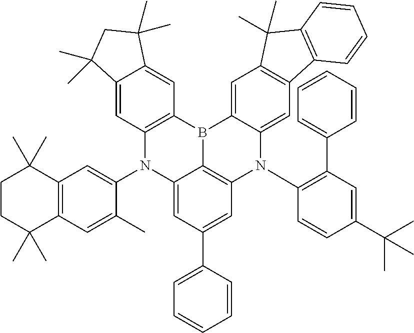 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)-c1ccccc1C6(C)C)C(C)(C)CC4(C)C)C(C)(C)CCC2(C)C]

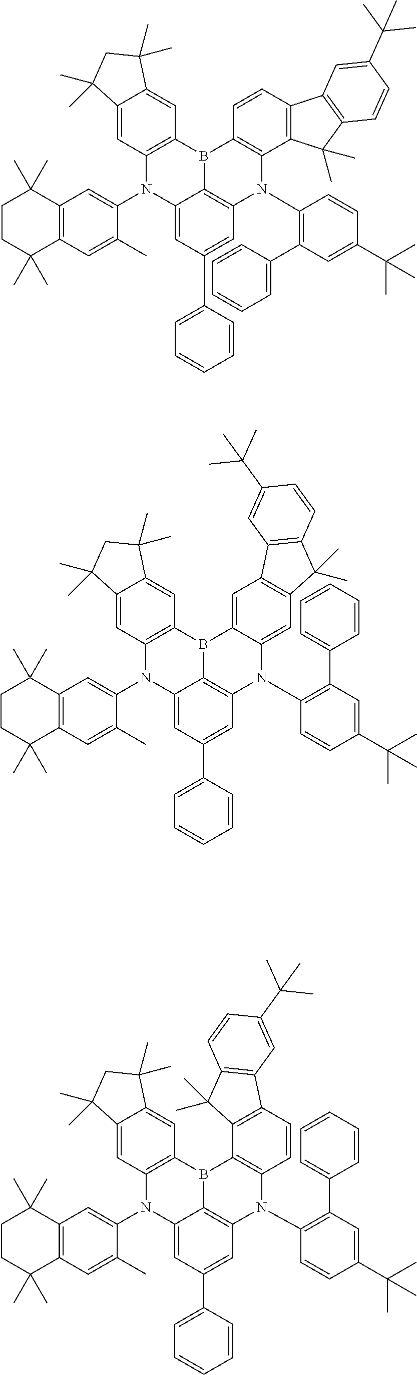 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7ccccc7)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(c13)C(C)(C)c1ccc(C(C)(C)C)cc1-5)C(C)(C)CC4(C)C)C(C)(C)CCC2(C)C]

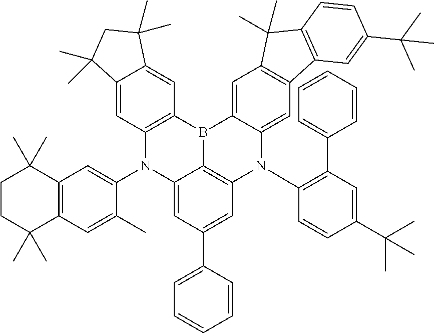 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)-c1cc(C(C)(C)C)ccc1C6(C)C)C(C)(C)CC4(C)C)C(C)(C)CCC2(C)C]

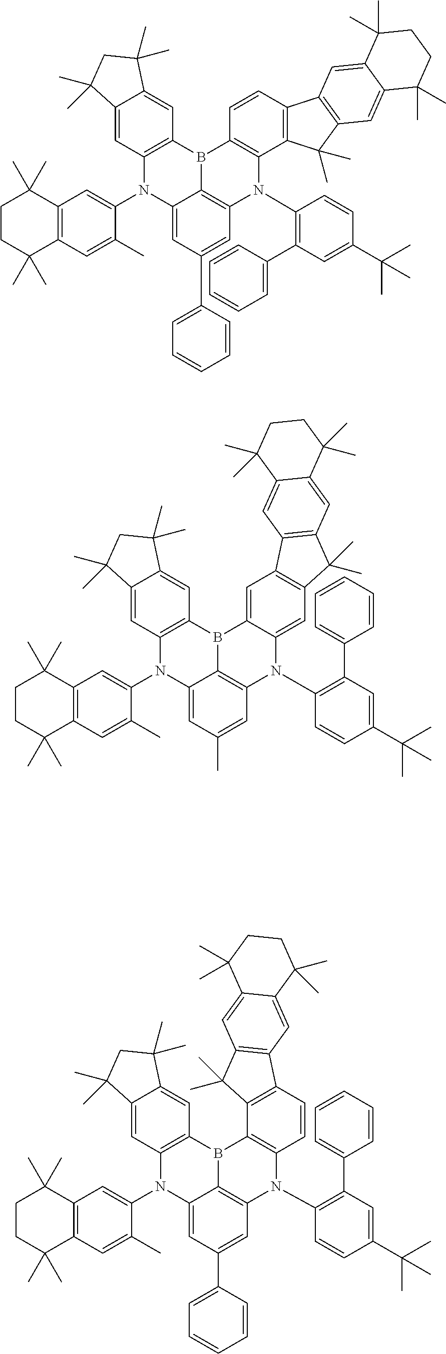 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)C(C)(C)c1cc3c(cc1-6)C(C)(C)CCC3(C)C)C(C)(C)CC4(C)C)C(C)(C)CCC2(C)C ; Cc1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1cc2c(cc1N1c3cc4c(cc3B3c5c1cc(-c1ccccc1)cc5N(c1ccc(C(C)(C)C)cc1-c1ccccc1)c1ccc5c(c13)C(C)(C)c1cc3c(cc1-5)C(C)(C)CCC3(C)C)C(C)(C)CC4(C)C)C(C)(C)CCC2(C)C]

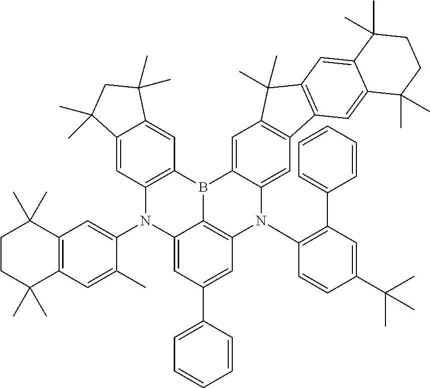 [SMILES: Cc1cc2c(cc1N1c3cc4c(cc3B3c5cc6c(cc5N(c5ccc(C(C)(C)C)cc5-c5ccccc5)c5cc(-c7ccccc7)cc1c53)-c1cc3c(cc1C6(C)C)C(C)(C)CCC3(C)C)C(C)(C)CC4(C)C)C(C)(C)CCC2(C)C]

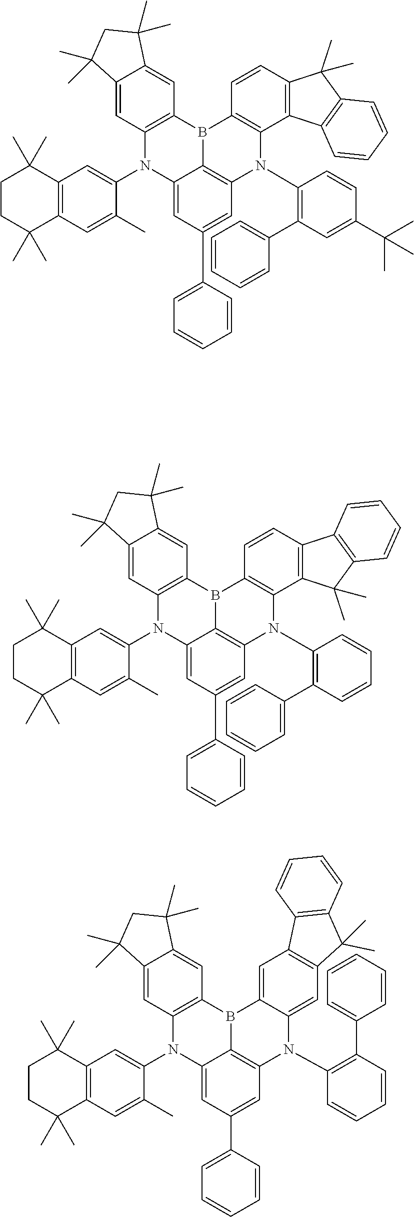 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)C(C)(C)c1ccccc1-6)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)C(C)(C)c1ccccc1-6)C(C)(C)CC4(C)C)C(C)(C)CCC2(C)C]

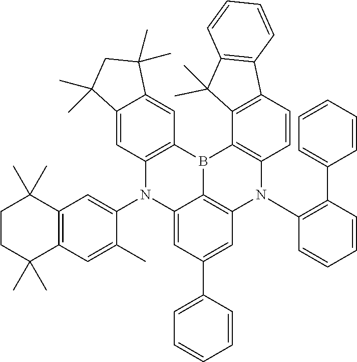 [SMILES: Cc1cc2c(cc1N1c3cc4c(cc3B3c5c1cc(-c1ccccc1)cc5N(c1ccccc1-c1ccccc1)c1ccc5c(c13)C(C)(C)c1ccccc1-5)C(C)(C)CC4(C)C)C(C)(C)CCC2(C)C]

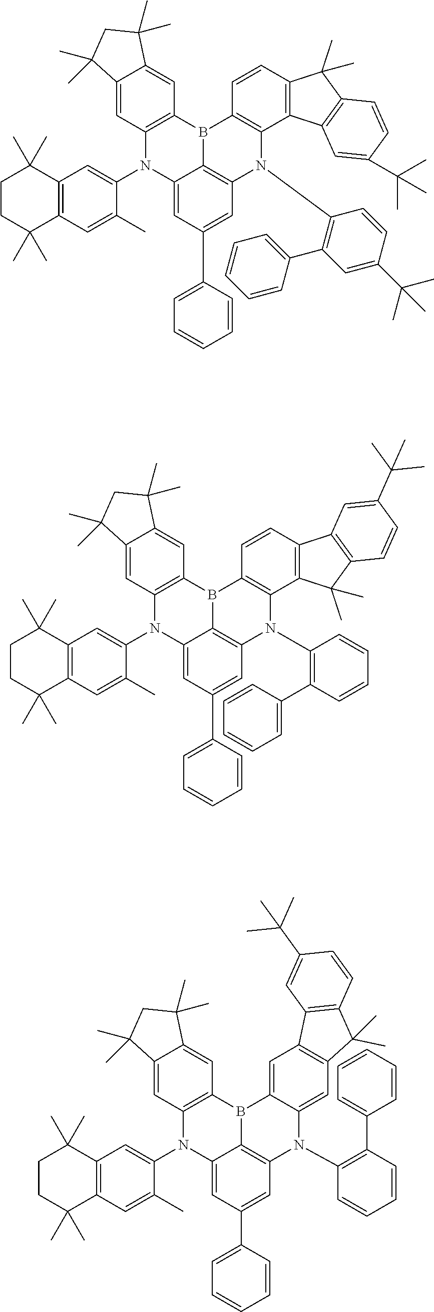 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)C(C)(C)c1ccc(C(C)(C)C)cc1-6)C(C)(C)CC4(C)C)C(C)(C)CCC2(C)C]

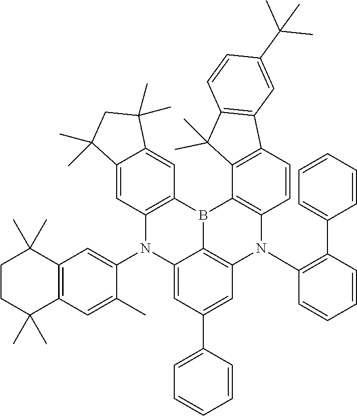 [SMILES: Cc1cc2c(cc1N1c3cc4c(cc3B3c5c1cc(-c1ccccc1)cc5N(c1ccccc1-c1ccccc1)c1ccc5c(c13)C(C)(C)c1ccc(C(C)(C)C)cc1-5)C(C)(C)CC4(C)C)C(C)(C)CCC2(C)C]

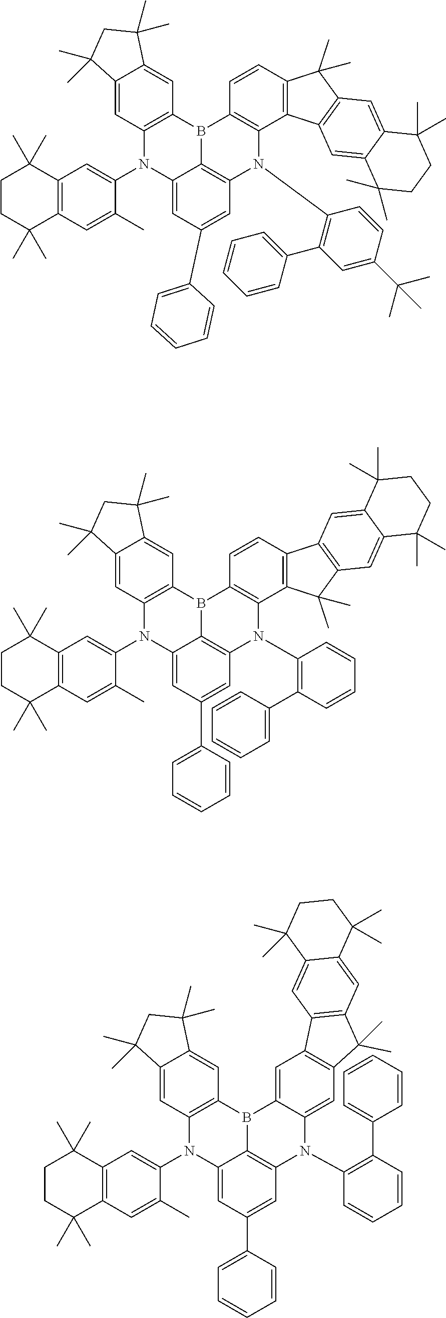 [SMILES: Cc1cc2c(cc1N1c3cc4c(cc3B3c5ccc6c(c5N(c5ccc(C(C)(C)C)cc5-c5ccccc5)c5cc(-c7ccccc7)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7ccccc7)cc1c53)C(C)(C)c1cc3c(cc1-6)C(C)(C)CCC3(C)C)C(C)(C)CC4(C)C)C(C)(C)CCC2(C)C]

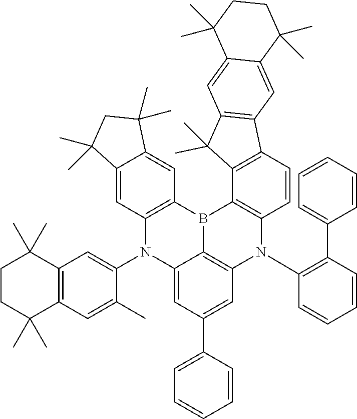 [SMILES: Cc1cc2c(cc1N1c3cc4c(cc3B3c5c1cc(-c1ccccc1)cc5N(c1ccccc1-c1ccccc1)c1ccc5c(c13)C(C)(C)c1cc3c(cc1-5)C(C)(C)CCC3(C)C)C(C)(C)CC4(C)C)C(C)(C)CCC2(C)C]

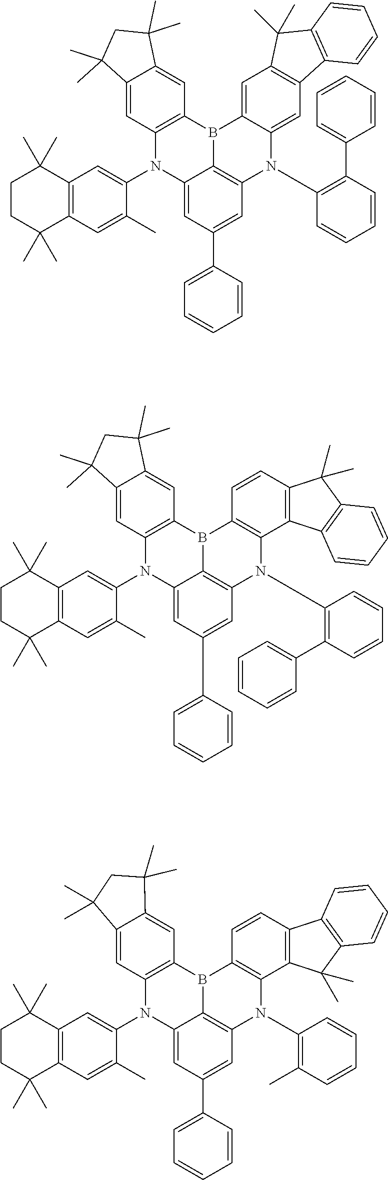 [SMILES: Cc1cc2c(cc1N1c3cc4c(cc3B3c5cc6c(cc5N(c5ccccc5-c5ccccc5)c5cc(-c7ccccc7)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccccc5C)c5cc(-c7ccccc7)cc1c53)C(C)(C)c1ccccc1-6)C(C)(C)CC4(C)C)C(C)(C)CCC2(C)C]

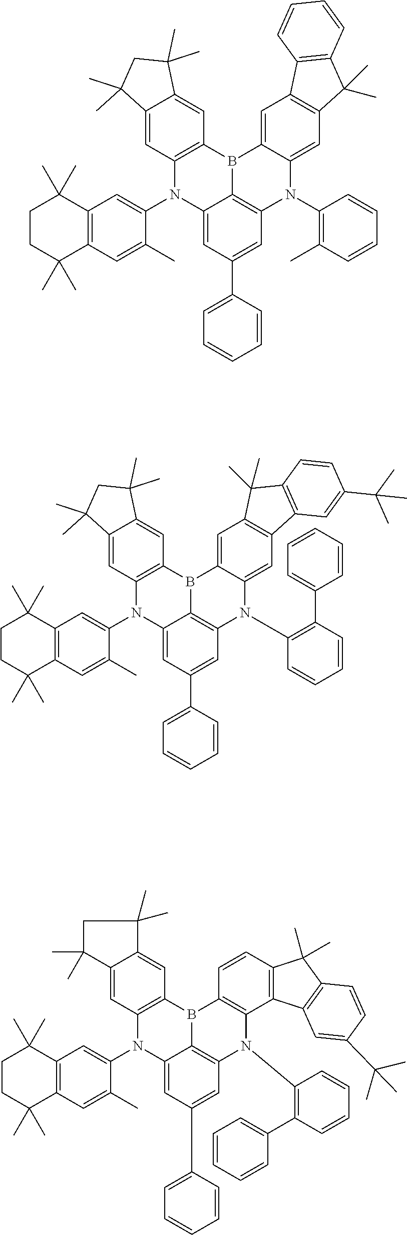 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)-c1ccccc1C3(C)C ; Cc1cc2c(cc1N1c3cc4c(cc3B3c5cc6c(cc5N(c5ccccc5-c5ccccc5)c5cc(-c7ccccc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7ccccc7)cc1c53)-c1cc(C(C)(C)C)ccc1C6(C)C)C(C)(C)CC4(C)C)C(C)(C)CCC2(C)C]

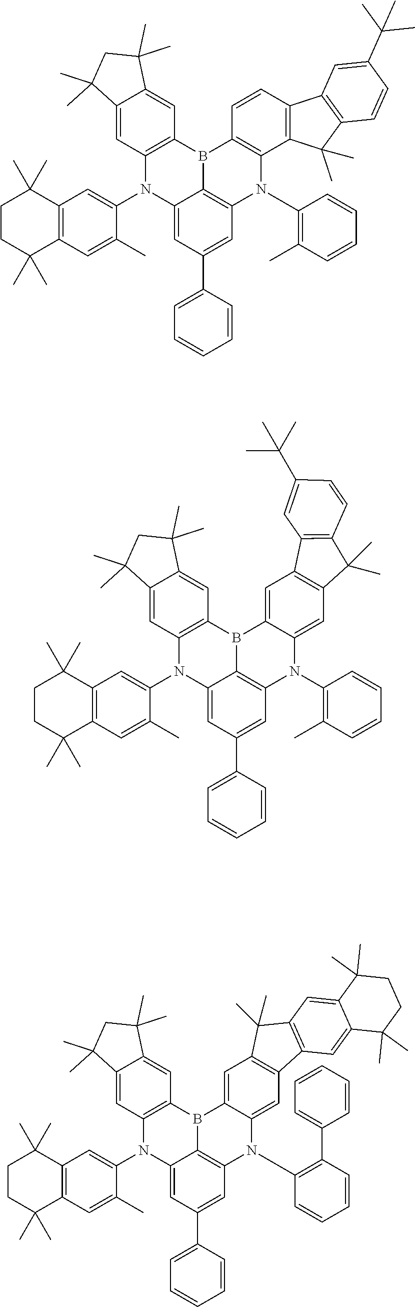 [SMILES: Cc1cc2c(cc1N1c3cc4c(cc3B3c5ccc6c(c5N(c5ccccc5C)c5cc(-c7ccccc7)cc1c53)C(C)(C)c1ccc(C(C)(C)C)cc1-6)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)-c1cc(C(C)(C)C)ccc1C3(C)C ; Cc1cc2c(cc1N1c3cc4c(cc3B3c5cc6c(cc5N(c5ccccc5-c5ccccc5)c5cc(-c7ccccc7)cc1c53)-c1cc3c(cc1C6(C)C)C(C)(C)CCC3(C)C)C(C)(C)CC4(C)C)C(C)(C)CCC2(C)C]

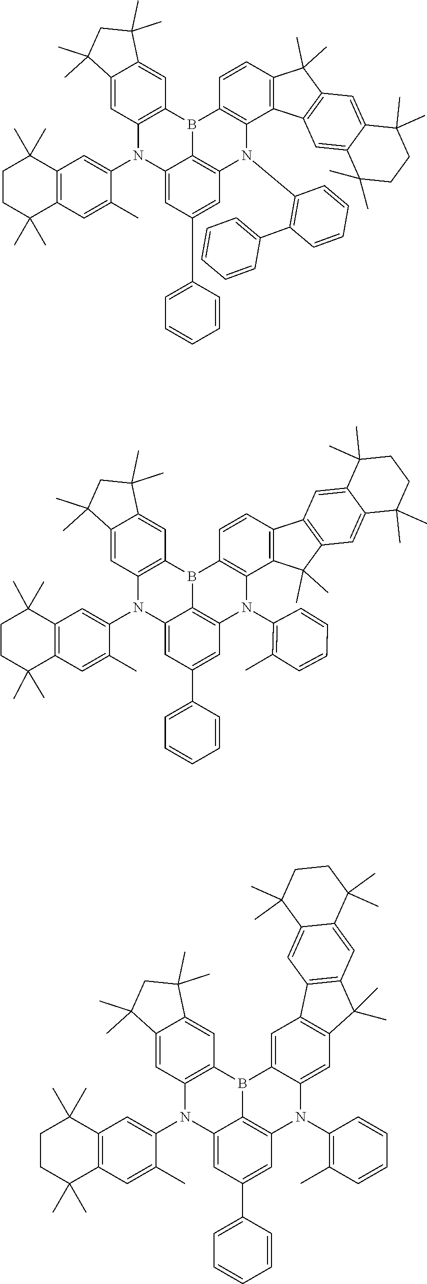 [SMILES: Cc1cc2c(cc1N1c3cc4c(cc3B3c5ccc6c(c5N(c5ccccc5-c5ccccc5)c5cc(-c7ccccc7)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5C)c5cc(-c7ccccc7)cc1c53)C(C)(C)c1cc3c(cc1-6)C(C)(C)CCC3(C)C)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)-c1cc2c(cc1C3(C)C)C(C)(C)CCC2(C)C]

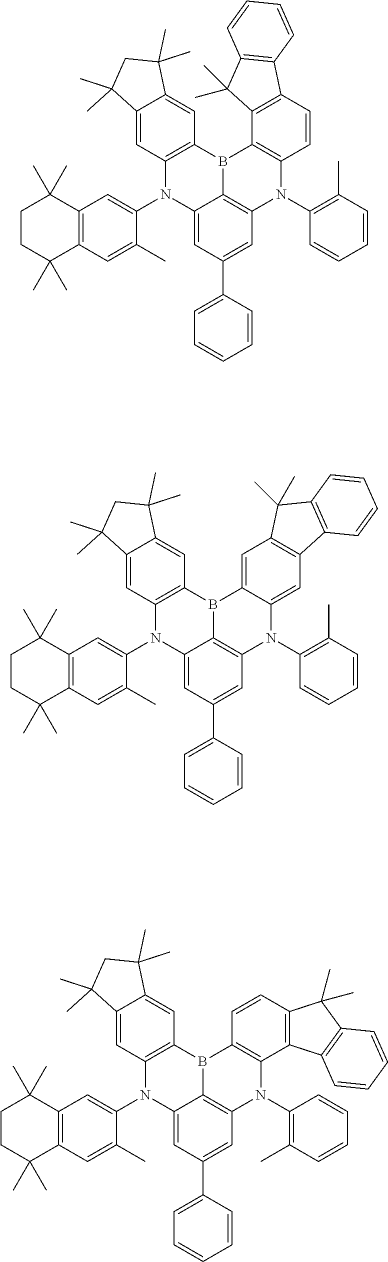 [SMILES: Cc1cc2c(cc1N1c3cc4c(cc3B3c5c1cc(-c1ccccc1)cc5N(c1ccccc1C)c1ccc5c(c13)C(C)(C)c1ccccc1-5)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)C(C)(C)c1ccccc1-3 ; Cc1cc2c(cc1N1c3cc4c(cc3B3c5ccc6c(c5N(c5ccccc5C)c5cc(-c7ccccc7)cc1c53)-c1ccccc1C6(C)C)C(C)(C)CC4(C)C)C(C)(C)CCC2(C)C]

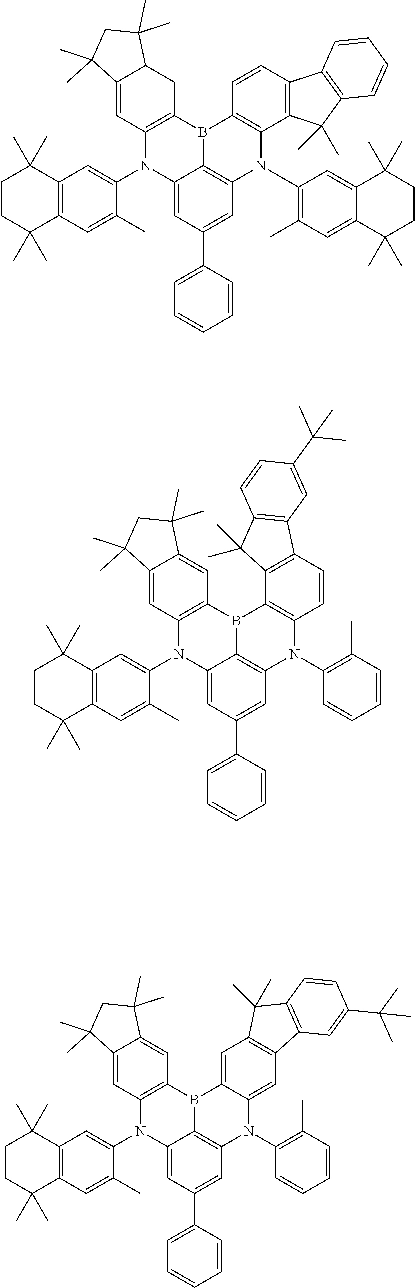 [SMILES: Cc1cc2c(cc1N1C3=C(CC4C(=C3)C(C)(C)CC4(C)C)B3c4ccc5c(c4N(c4cc6c(cc4C)C(C)(C)CCC6(C)C)c4cc(-c6ccccc6)cc1c43)C(C)(C)c1ccccc1-5)C(C)(C)CCC2(C)C ; Cc1cc2c(cc1N1c3cc4c(cc3B3c5c1cc(-c1ccccc1)cc5N(c1ccccc1C)c1ccc5c(c13)C(C)(C)c1ccc(C(C)(C)C)cc1-5)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)C(C)(C)c1ccc(C(C)(C)C)cc1-3]

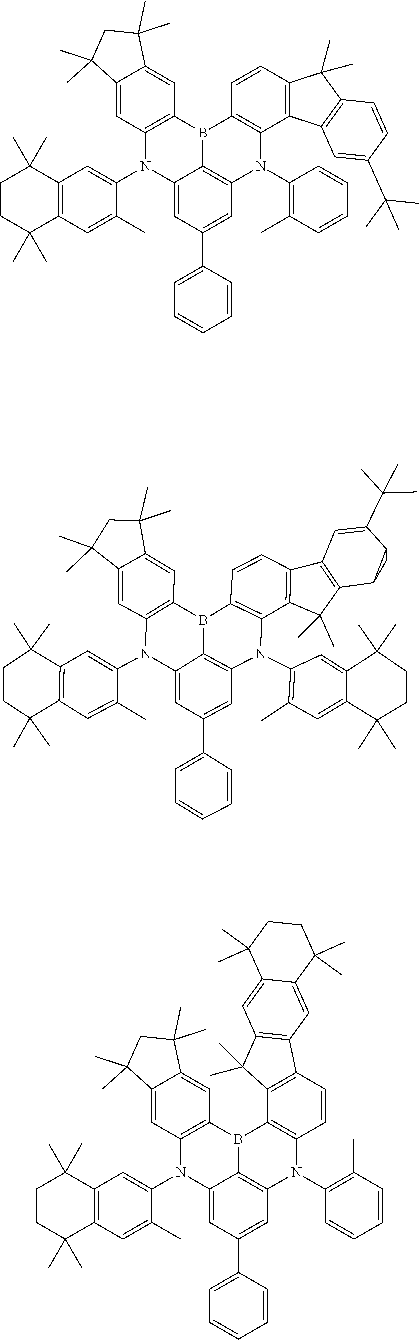 [SMILES: Cc1cc2c(cc1N1c3cc4c(cc3B3c5ccc6c(c5N(c5ccccc5C)c5cc(-c7ccccc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7ccccc7)cc1c53)C(C)(C)C1=C6C=C(C(C)(C)C)C3CC13)C(C)(C)CC4(C)C)C(C)(C)CCC2(C)C ; Cc1cc2c(cc1N1c3cc4c(cc3B3c5c1cc(-c1ccccc1)cc5N(c1ccccc1C)c1ccc5c(c13)C(C)(C)c1cc3c(cc1-5)C(C)(C)CCC3(C)C)C(C)(C)CC4(C)C)C(C)(C)CCC2(C)C]

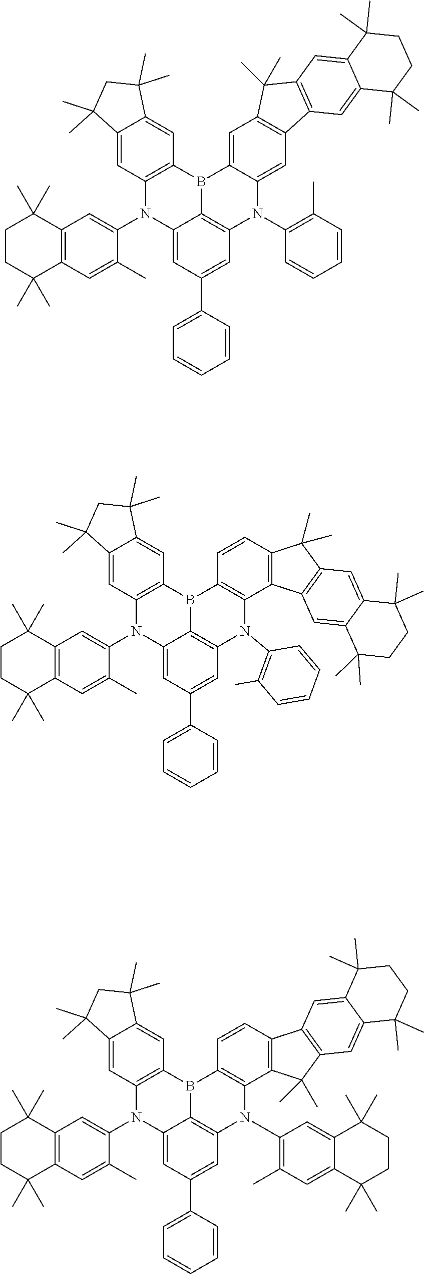 [SMILES: Cc1ccccc1N1c2cc3c(cc2B2c4cc5c(cc4N(c4cc6c(cc4C)C(C)(C)CCC6(C)C)c4cc(-c6ccccc6)cc1c42)C(C)(C)CC5(C)C)C(C)(C)c1cc2c(cc1-3)C(C)(C)CCC2(C)C ; Cc1cc2c(cc1N1c3cc4c(cc3B3c5ccc6c(c5N(c5ccccc5C)c5cc(-c7ccccc7)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7ccccc7)cc1c53)C(C)(C)c1cc3c(cc1-6)C(C)(C)CCC3(C)C)C(C)(C)CC4(C)C)C(C)(C)CCC2(C)C]

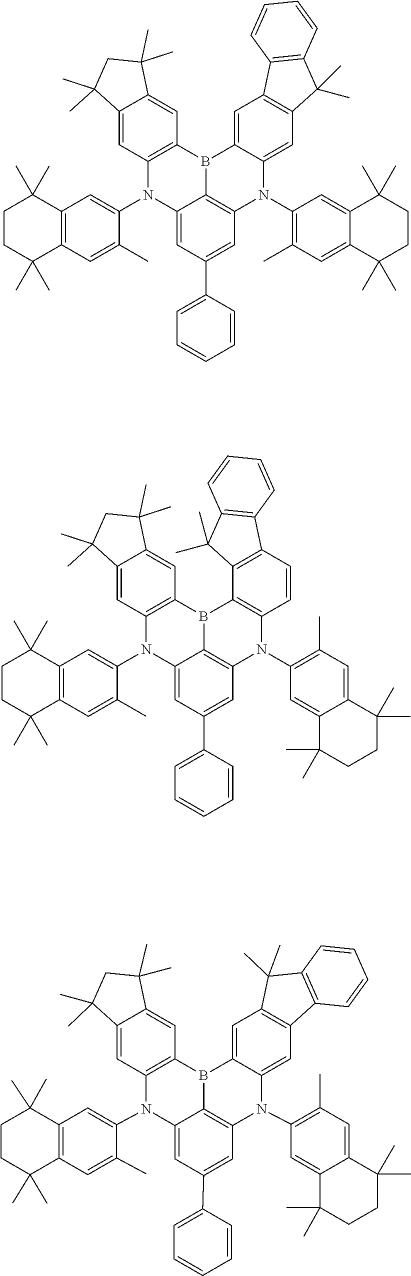 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)c1ccccc1-6)C(C)(C)CC4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(c13)C(C)(C)c1ccccc1-5)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)CC6(C)C)C(C)(C)c1ccccc1-4)C(C)(C)CCC2(C)C]

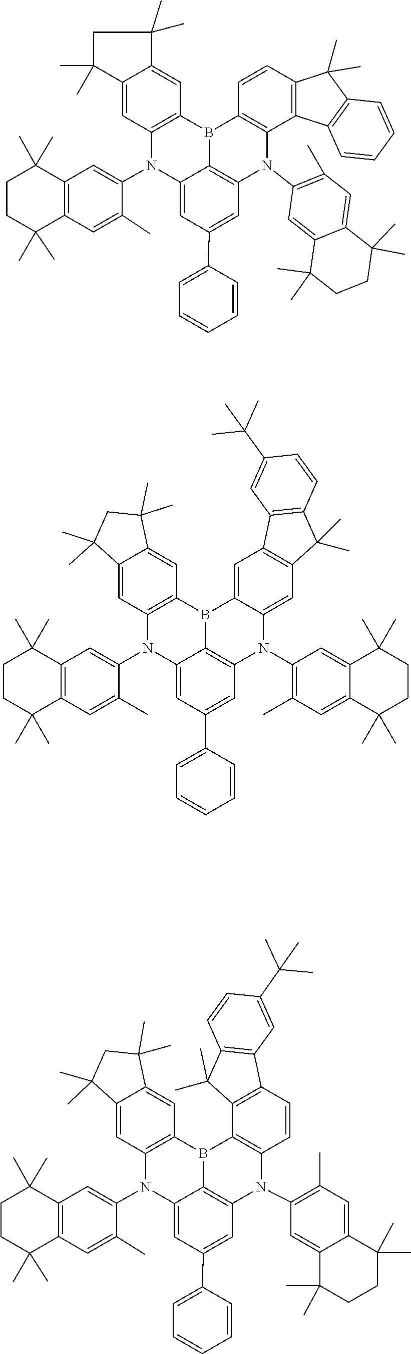 [SMILES: Cc1cc2c(cc1N1c3cc4c(cc3B3c5ccc6c(c5N(c5cc7c(cc5C)C(C)(C)CCC7(C)C)c5cc(-c7ccccc7)cc1c53)-c1ccccc1C6(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(-c1ccccc1)cc5N(c1cc5c(cc1C)C(C)(C)CCC5(C)C)c1ccc5c(c13)C(C)(C)c1ccc(C(C)(C)C)cc1-5)C(C)(C)CC4(C)C)C(C)(C)CCC2(C)C]

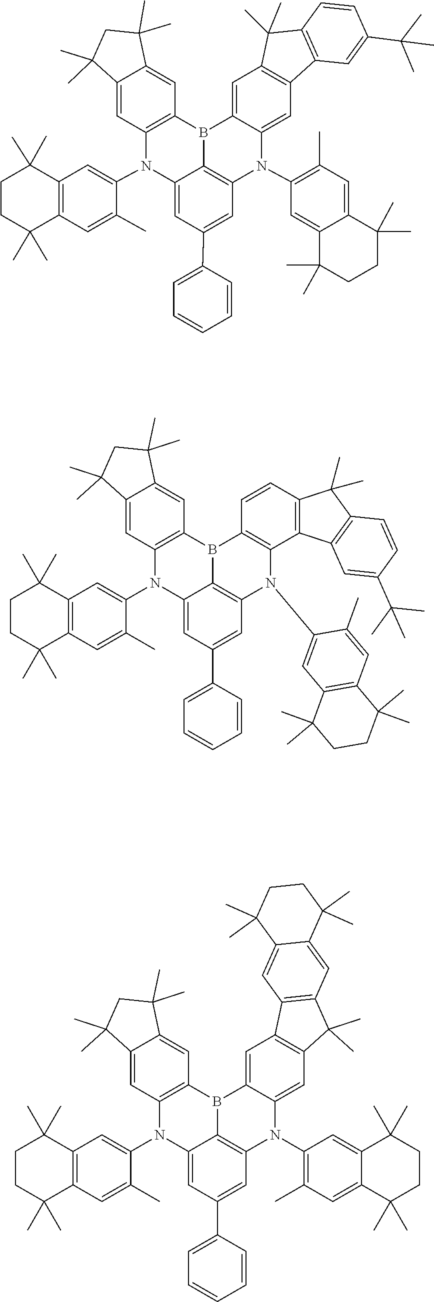 [SMILES: Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)CC6(C)C)C(C)(C)c1ccc(C(C)(C)C)cc1-4)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7ccccc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)c1cc3c(cc1-6)C(C)(C)CCC3(C)C)C(C)(C)CC4(C)C)C(C)(C)CCC2(C)C]

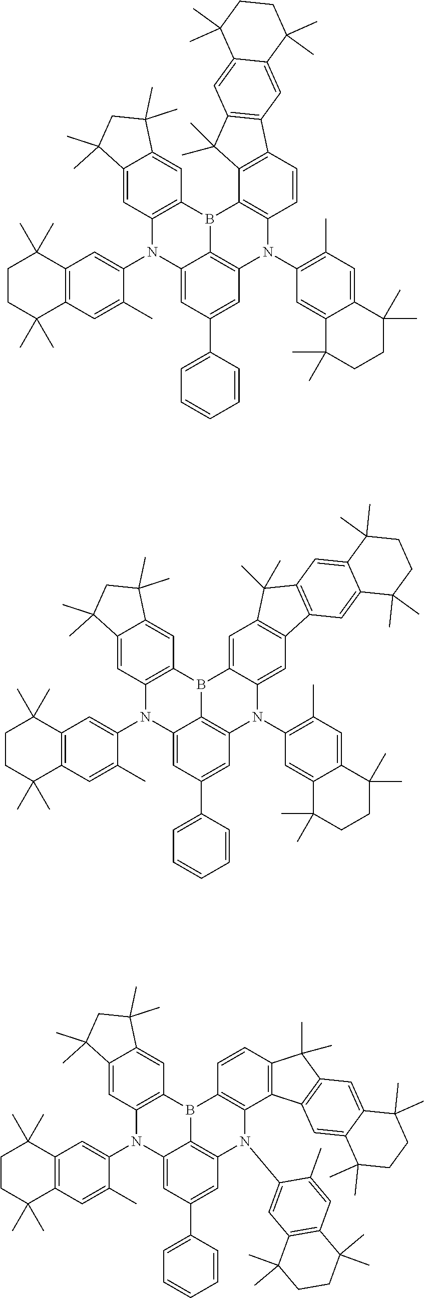 [SMILES: Cc1cc2c(cc1N1c3cc4c(cc3B3c5c1cc(-c1ccccc1)cc5N(c1cc5c(cc1C)C(C)(C)CCC5(C)C)c1ccc5c(c13)C(C)(C)c1cc3c(cc1-5)C(C)(C)CCC3(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7ccccc7)cc1c53)C(C)(C)CC6(C)C)C(C)(C)c1cc3c(cc1-4)C(C)(C)CCC3(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7ccccc7)cc1c53)-c1cc3c(cc1C6(C)C)C(C)(C)CCC3(C)C)C(C)(C)CC4(C)C)C(C)(C)CCC2(C)C]

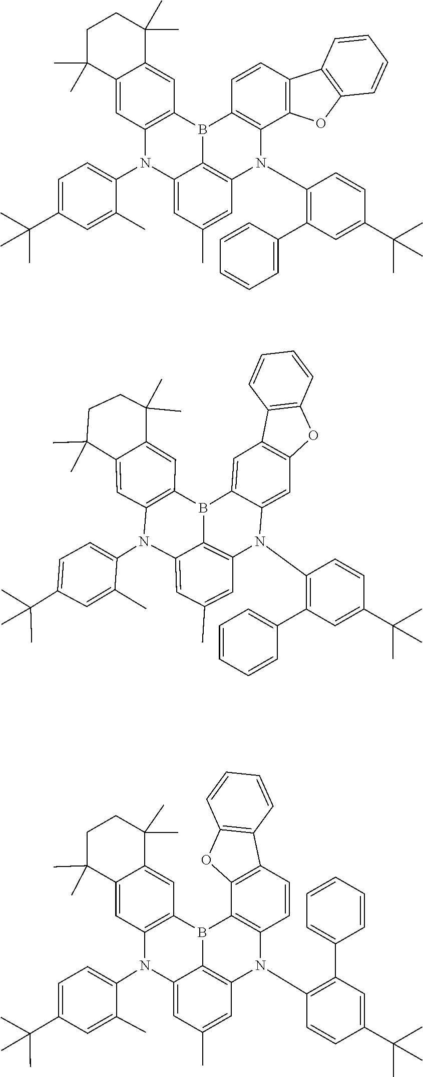

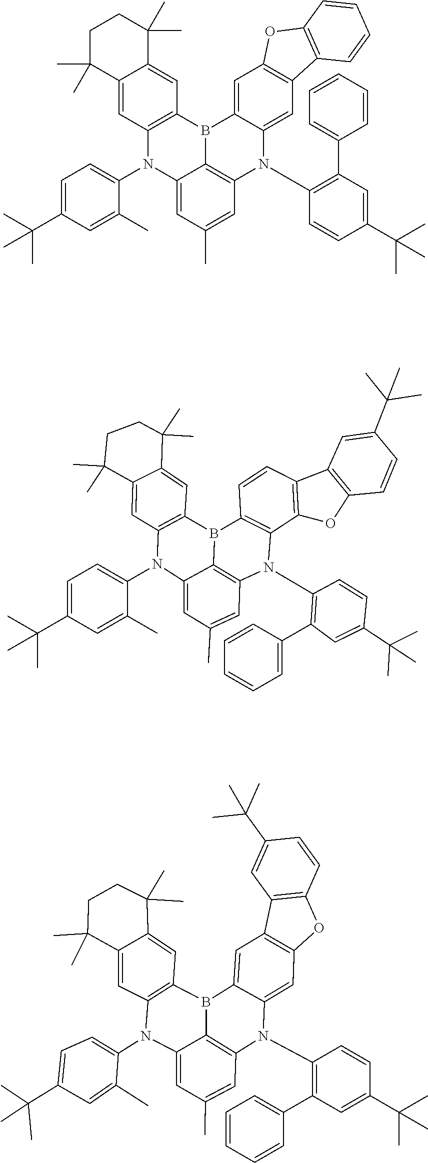

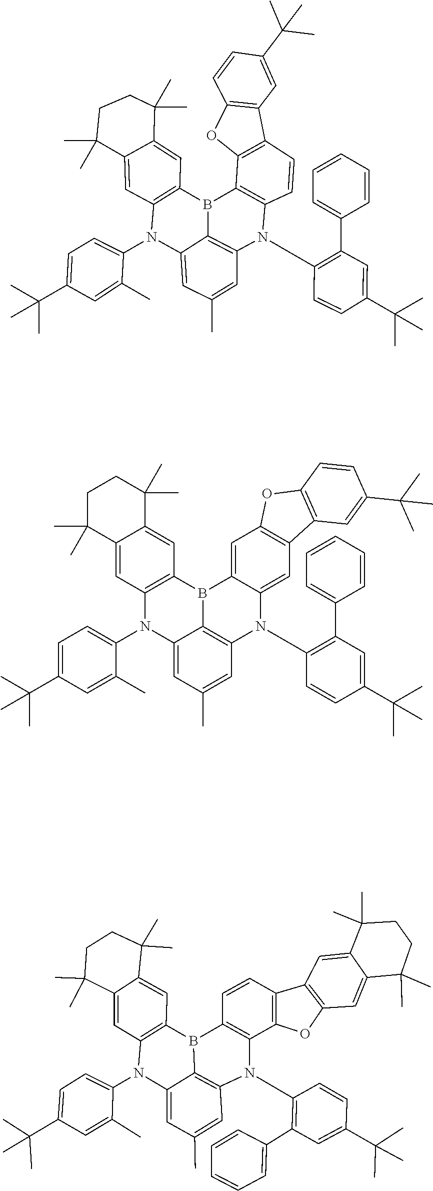

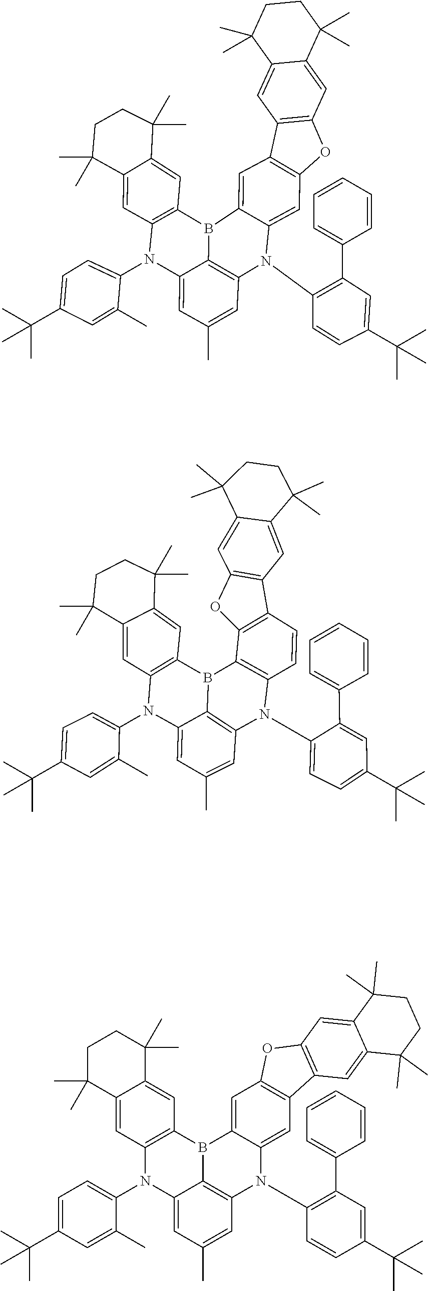

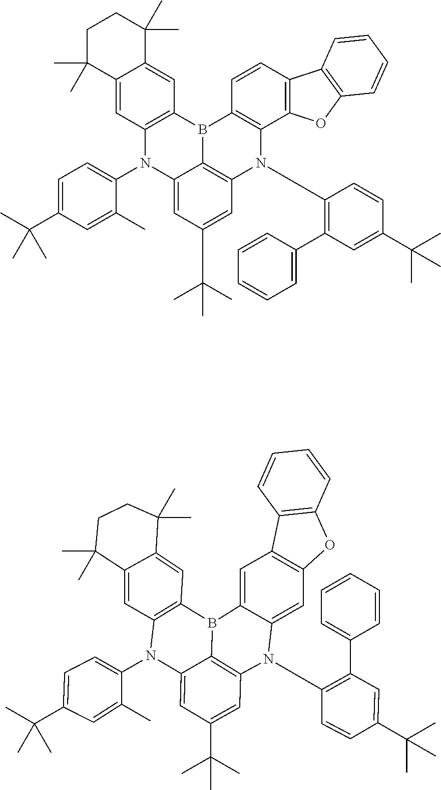

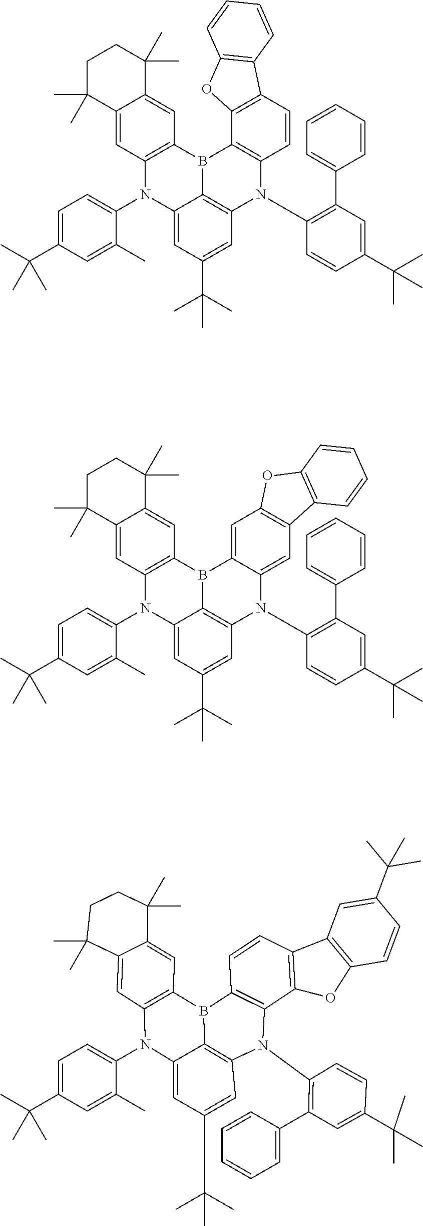

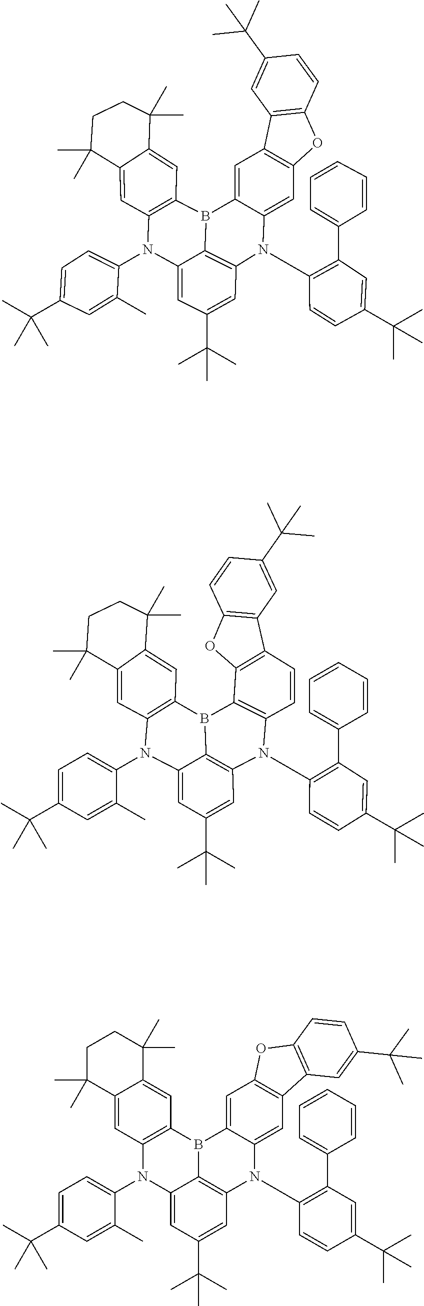

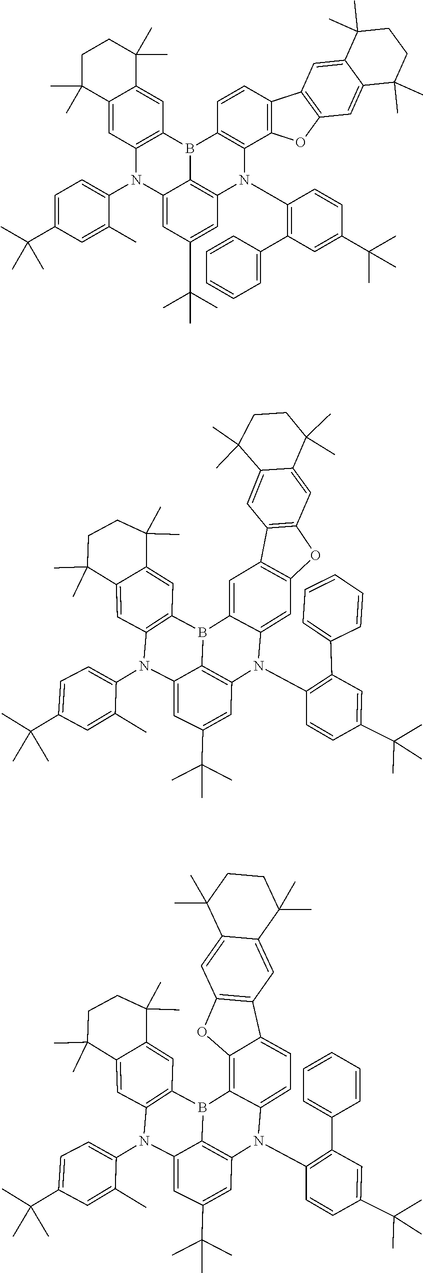

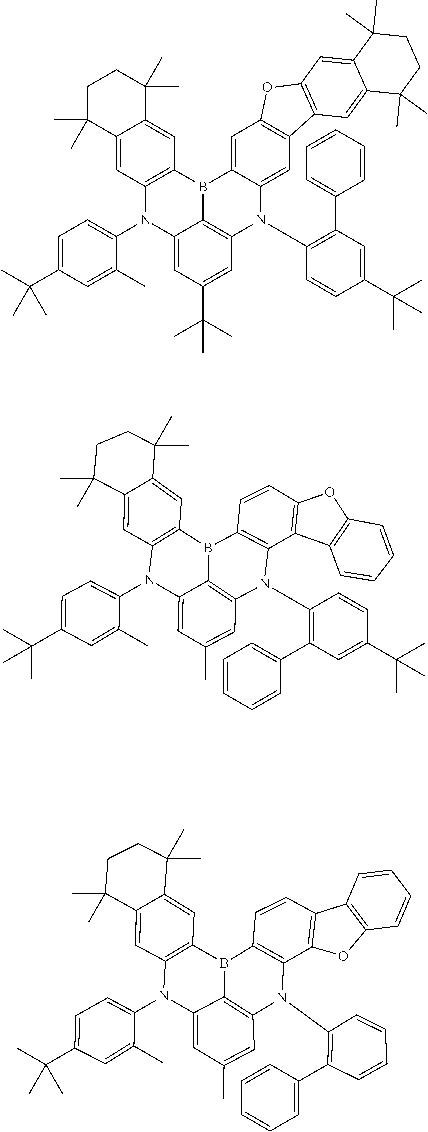

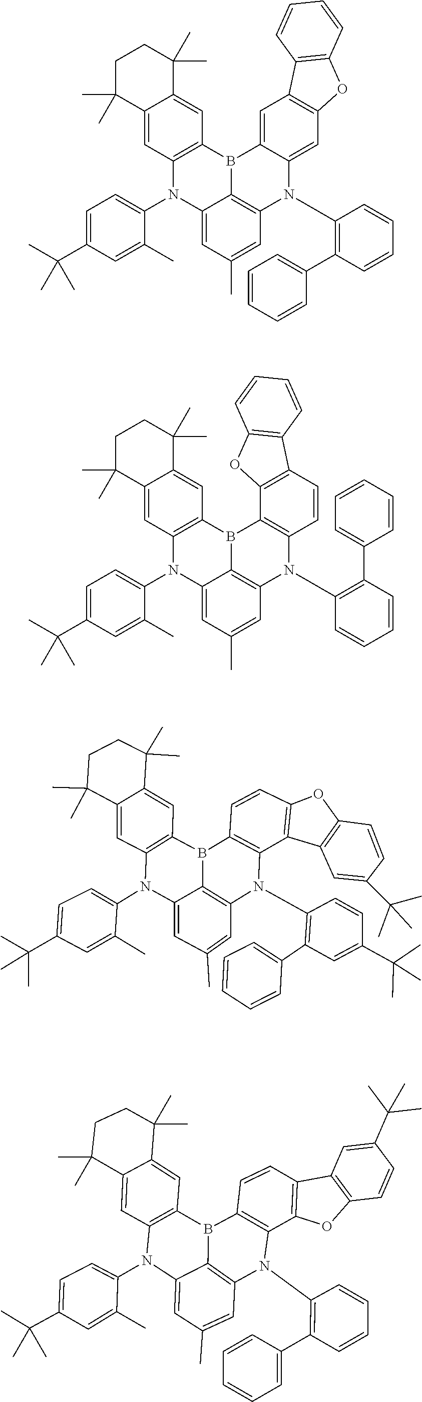

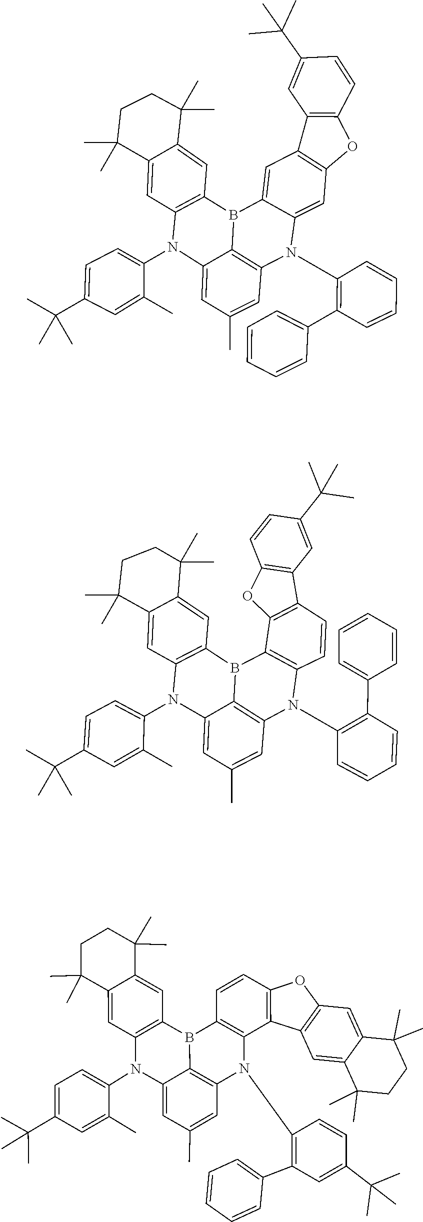 [SMILES: Cc1cc2c3c(c1)N(c1ccccc1-c1ccccc1)c1cc4oc5ccc(C(C)(C)C)cc5c4cc1B3c1cc3c(cc1N2c1ccc(C(C)(C)C)cc1C)C(C)(C)CCC3(C)C ; Cc1cc2c3c(c1)N(c1ccccc1-c1ccccc1)c1ccc4c(oc5ccc(C(C)(C)C)cc54)c1B3c1cc3c(cc1N2c1ccc(C(C)(C)C)cc1C)C(C)(C)CCC3(C)C ; Cc1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc(C(C)(C)C)cc1C)C(C)(C)CCC3(C)C]

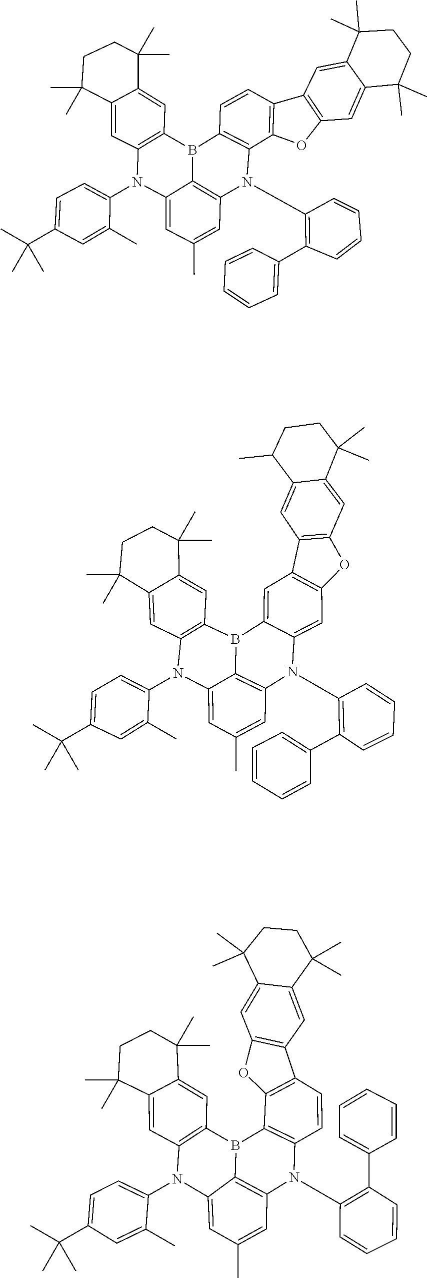

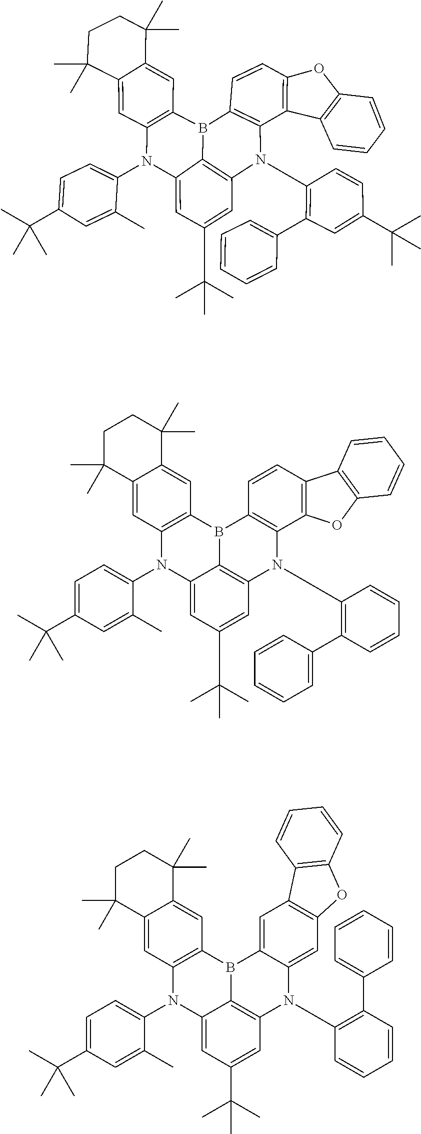

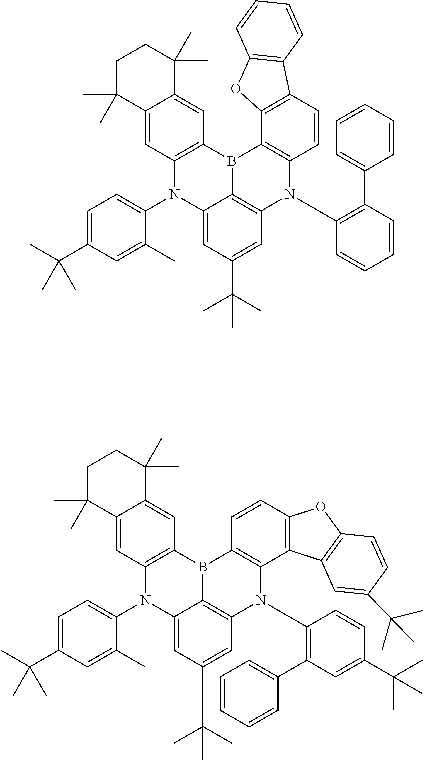 [SMILES: Cc1cc(C(C)(C)C)ccc1N1c2cc3c(cc2B2c4c1cc(C(C)(C)C)cc4N(c1ccccc1-c1ccccc1)c1ccc4c(oc5ccccc54)c12)C(C)(C)CCC3(C)C ; Cc1cc(C(C)(C)C)ccc1N1c2cc3c(cc2B2c4ccc5oc6ccc(C(C)(C)C)cc6c5c4N(c4ccc(C(C)(C)C)cc4-c4ccccc4)c4cc(C(C)(C)C)cc1c42)C(C)(C)CCC3(C)C]

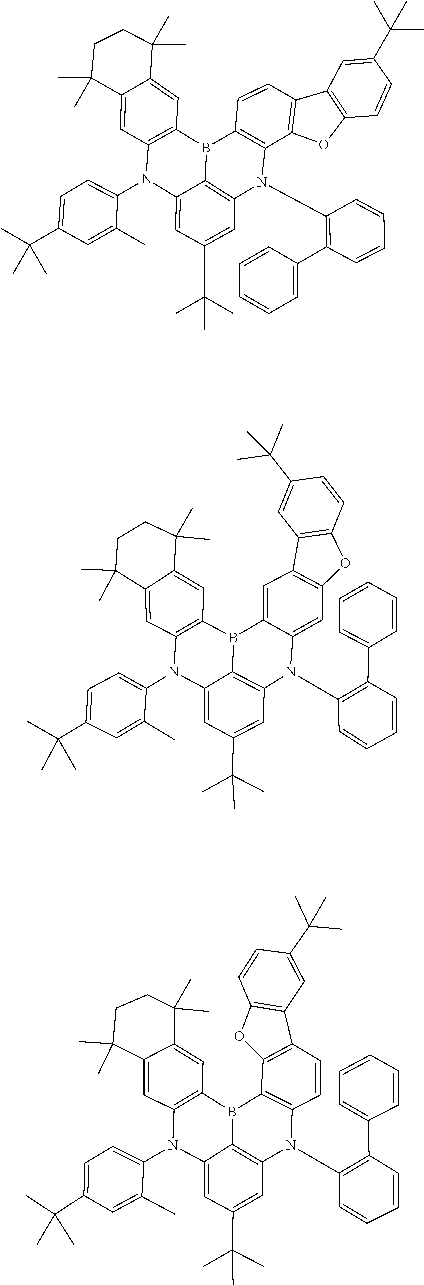

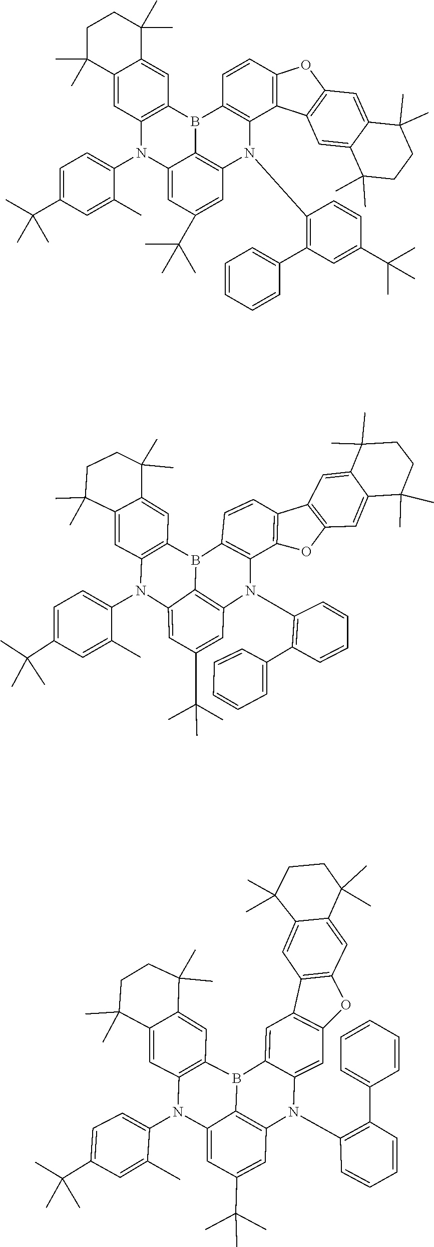

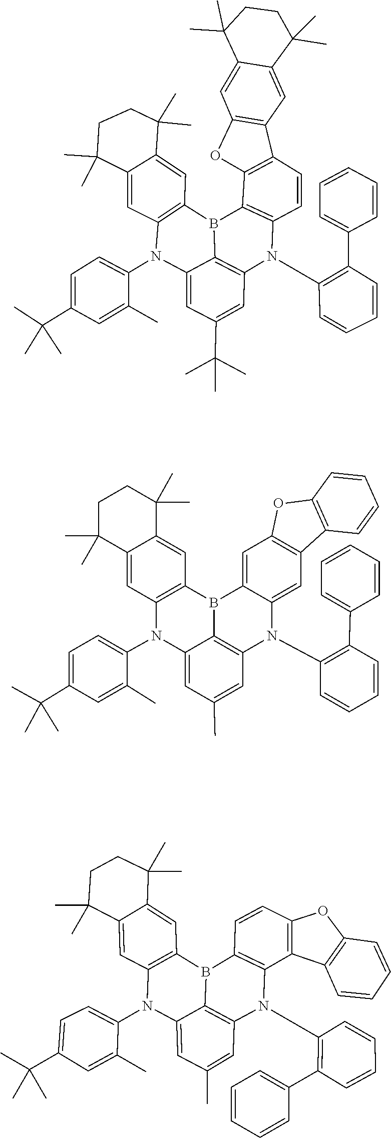 [SMILES: Cc1cc(C(C)(C)C)ccc1N1c2cc3c(cc2B2c4c1cc(C(C)(C)C)cc4N(c1ccccc1-c1ccccc1)c1ccc4c(oc5cc6c(cc54)C(C)(C)CCC6(C)C)c12)C(C)(C)CCC3(C)C ; Cc1cc2c3c(c1)N(c1ccccc1-c1ccccc1)c1cc4c(cc1B3c1cc3c(cc1N2c1ccc(C(C)(C)C)cc1C)C(C)(C)CCC3(C)C)oc1ccccc14 ; Cc1cc2c3c(c1)N(c1ccccc1-c1ccccc1)c1c(ccc4oc5ccccc5c14)B3c1cc3c(cc1N2c1ccc(C(C)(C)C)cc1C)C(C)(C)CCC3(C)C]

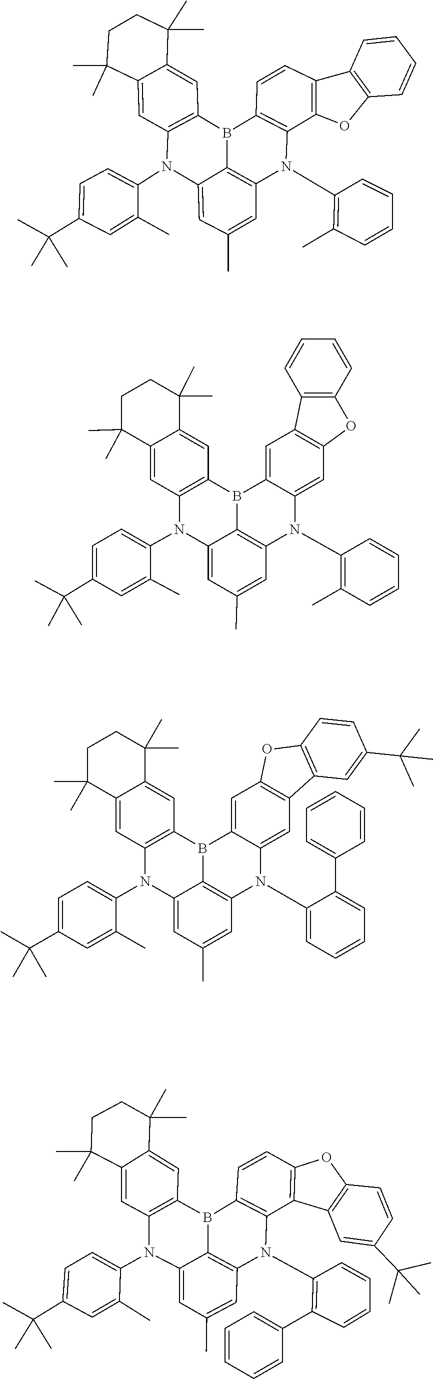

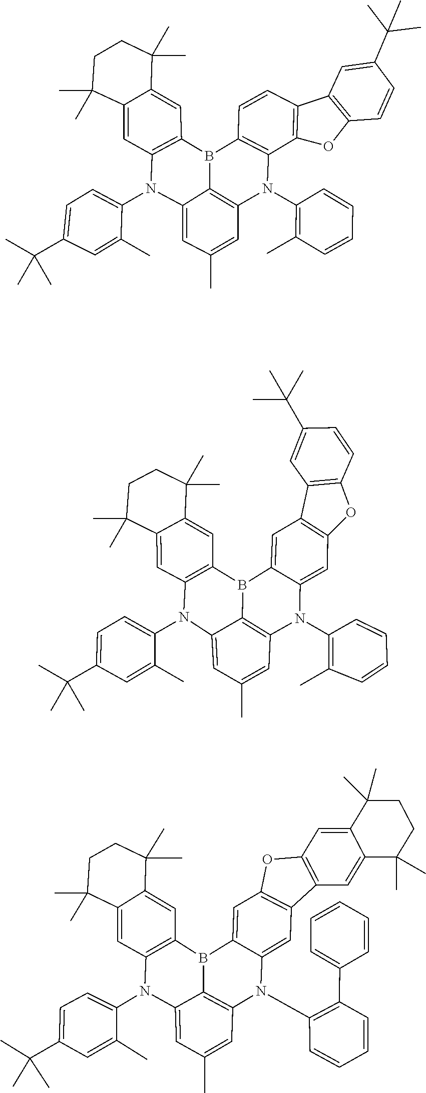

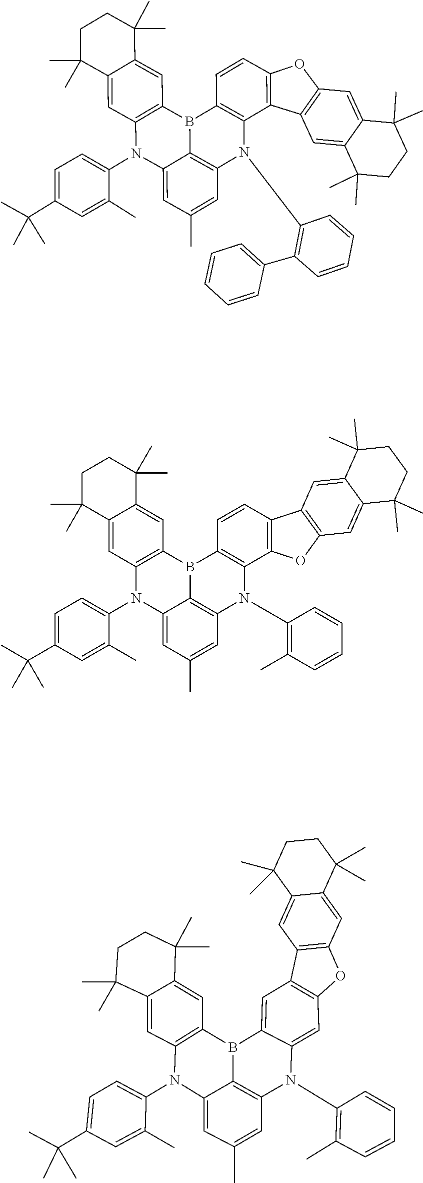

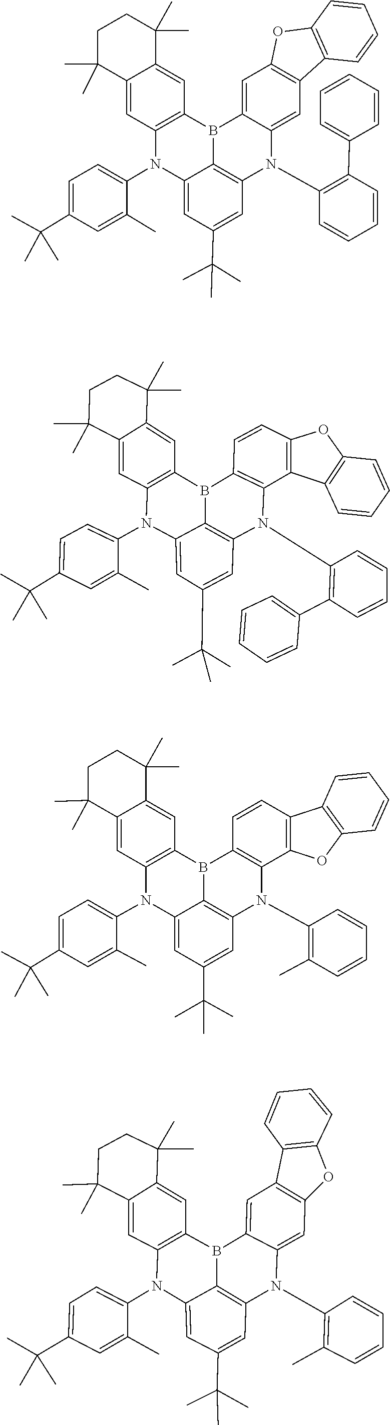 [SMILES: Cc1cc(C(C)(C)C)ccc1N1c2cc3c(cc2B2c4cc5oc6ccccc6c5cc4N(c4ccccc4-c4ccccc4)c4cc(C(C)(C)C)cc1c42)C(C)(C)CCC3(C)C ; Cc1cc(C(C)(C)C)ccc1N1c2cc3c(cc2B2c4ccc5oc6ccccc6c5c4N(c4ccccc4-c4ccccc4)c4cc(C(C)(C)C)cc1c42)C(C)(C)CCC3(C)C ; Cc1cc(C(C)(C)C)ccc1N1c2cc3c(cc2B2c4ccc5c(oc6ccccc65)c4N(c4ccccc4C)c4cc(C(C)(C)C)cc1c42)C(C)(C)CCC3(C)C ; Cc1cc(C(C)(C)C)ccc1N1c2cc3c(cc2B2c4cc5c(cc4N(c4ccccc4C)c4cc(C(C)(C)C)cc1c42)oc1ccccc15)C(C)(C)CCC3(C)C]

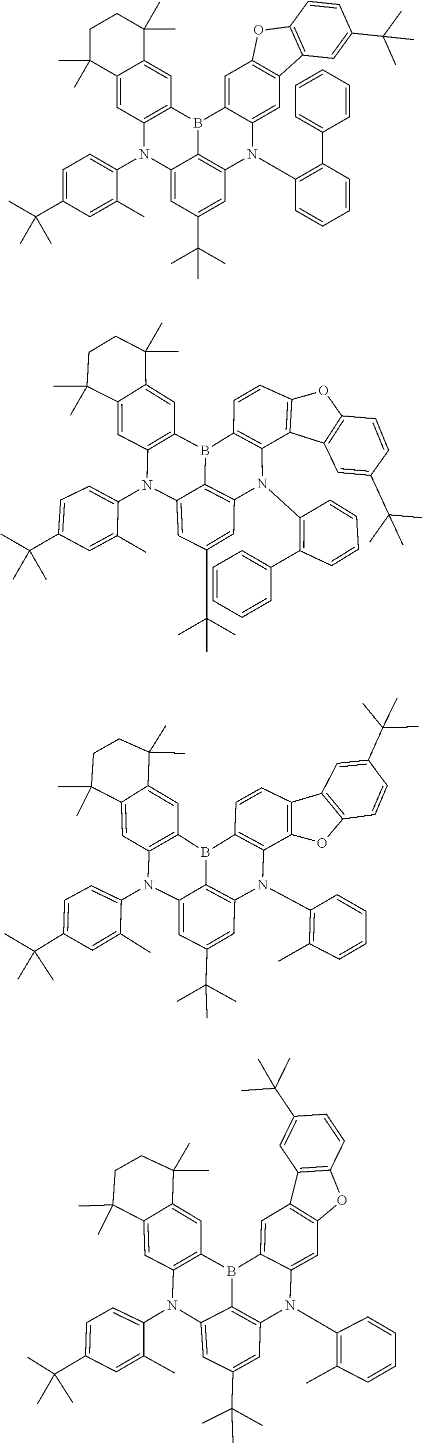

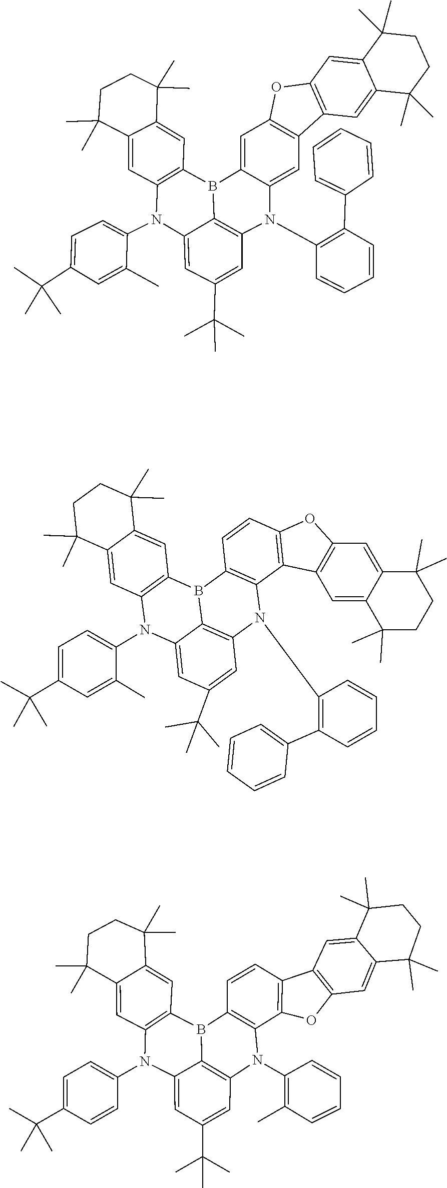

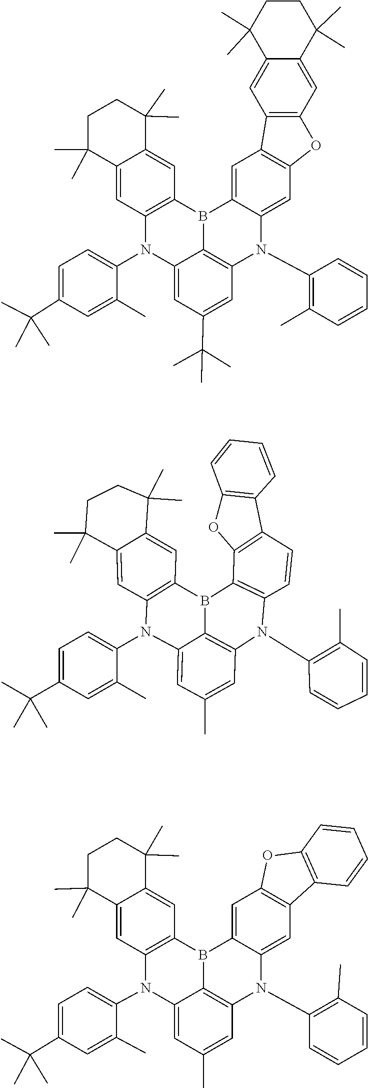 [SMILES: Cc1cc(C(C)(C)C)ccc1N1c2cc3c(cc2B2c4cc5c(cc4N(c4ccccc4C)c4cc(C(C)(C)C)cc1c42)oc1cc2c(cc15)C(C)(C)CCC2(C)C)C(C)(C)CCC3(C)C ; Cc1cc2c3c(c1)N(c1ccccc1C)c1ccc4c(oc5ccccc54)c1B3c1cc3c(cc1N2c1ccc(C(C)(C)C)cc1C)C(C)(C)CCC3(C)C ; Cc1cc2c3c(c1)N(c1ccccc1C)c1cc4c(cc1B3c1cc3c(cc1N2c1ccc(C(C)(C)C)cc1C)C(C)(C)CCC3(C)C)oc1ccccc14]

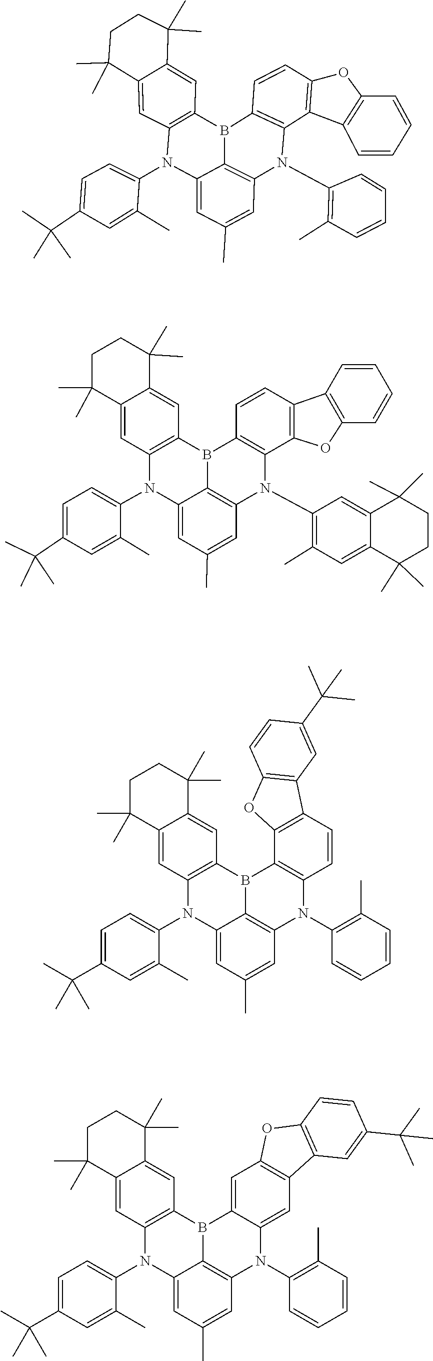 [SMILES: Cc1cc2c3c(c1)N(c1ccccc1C)c1c(ccc4oc5ccccc5c14)B3c1cc3c(cc1N2c1ccc(C(C)(C)C)cc1C)C(C)(C)CCC3(C)C ; Cc1cc2c3c(c1)N(c1cc4c(cc1C)C(C)(C)CCC4(C)C)c1c(ccc4c1oc1ccccc14)B3c1cc3c(cc1N2c1ccc(C(C)(C)C)cc1C)C(C)(C)CCC3(C)C ; Cc1cc2c3c(c1)N(c1ccccc1C)c1ccc4c(oc5ccc(C(C)(C)C)cc54)c1B3c1cc3c(cc1N2c1ccc(C(C)(C)C)cc1C)C(C)(C)CCC3(C)C ; Cc1cc2c3c(c1)N(c1ccccc1C)c1cc4c(cc1B3c1cc3c(cc1N2c1ccc(C(C)(C)C)cc1C)C(C)(C)CCC3(C)C)oc1ccc(C(C)(C)C)cc14]

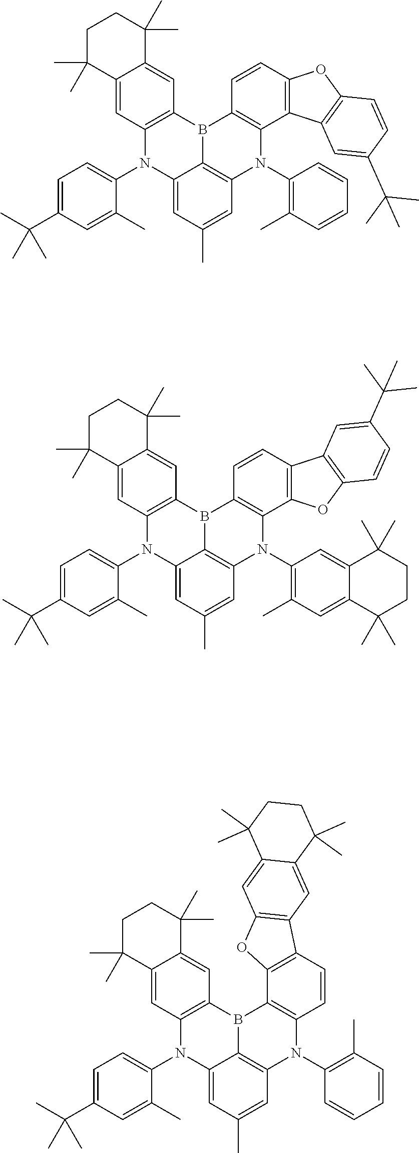

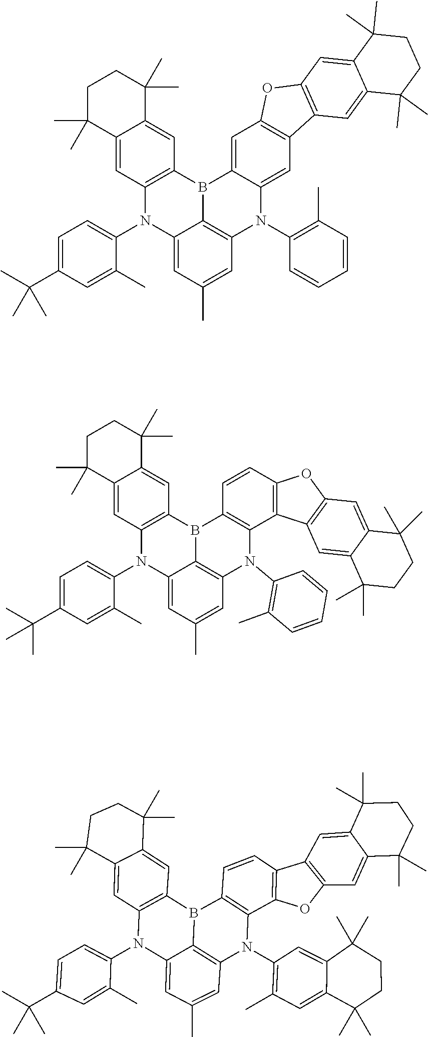

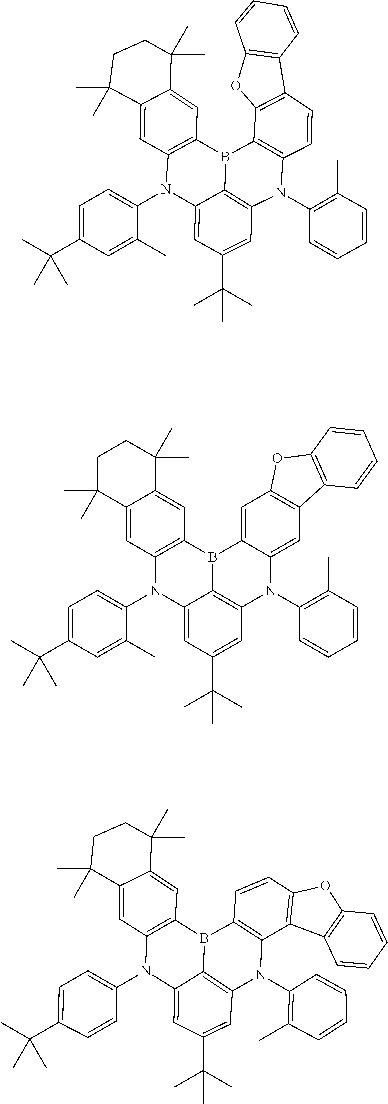 [SMILES: Cc1cc(C(C)(C)C)ccc1N1c2cc3c(cc2B2c4c1cc(C(C)(C)C)cc4N(c1ccccc1C)c1ccc4c(oc5ccccc54)c12)C(C)(C)CCC3(C)C ; Cc1cc(C(C)(C)C)ccc1N1c2cc3c(cc2B2c4cc5oc6ccccc6c5cc4N(c4ccccc4C)c4cc(C(C)(C)C)cc1c42)C(C)(C)CCC3(C)C ; Cc1ccccc1N1c2cc(C(C)(C)C)cc3c2B(c2cc4c(cc2N3c2ccc(C(C)(C)C)cc2)C(C)(C)CCC4(C)C)c2ccc3oc4ccccc4c3c21]

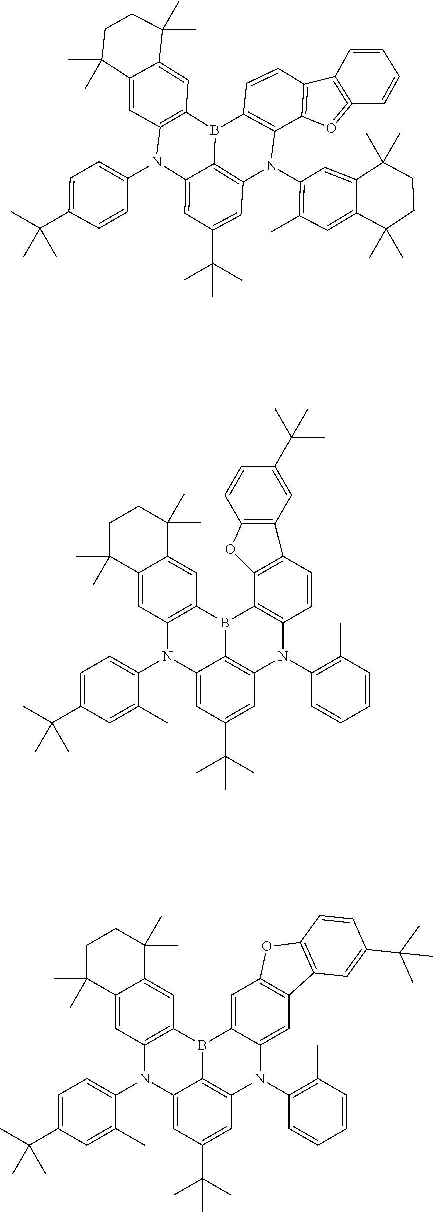

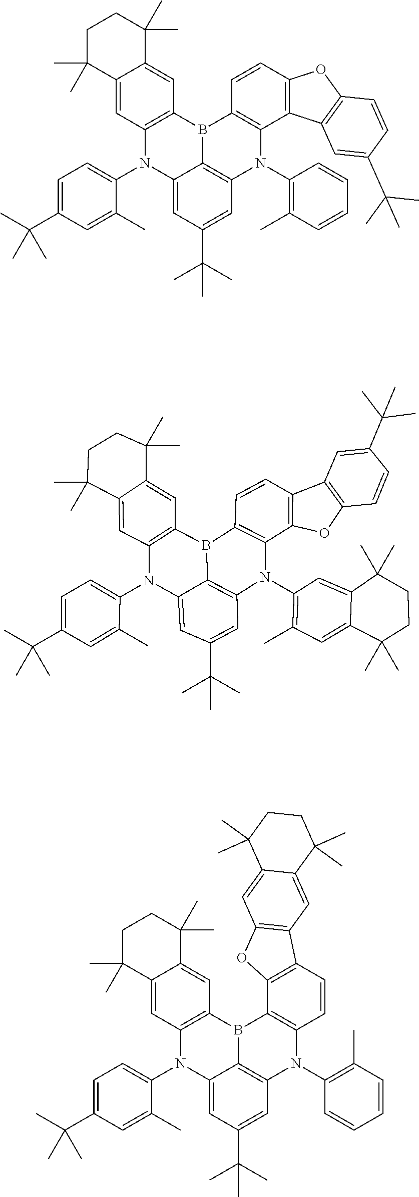

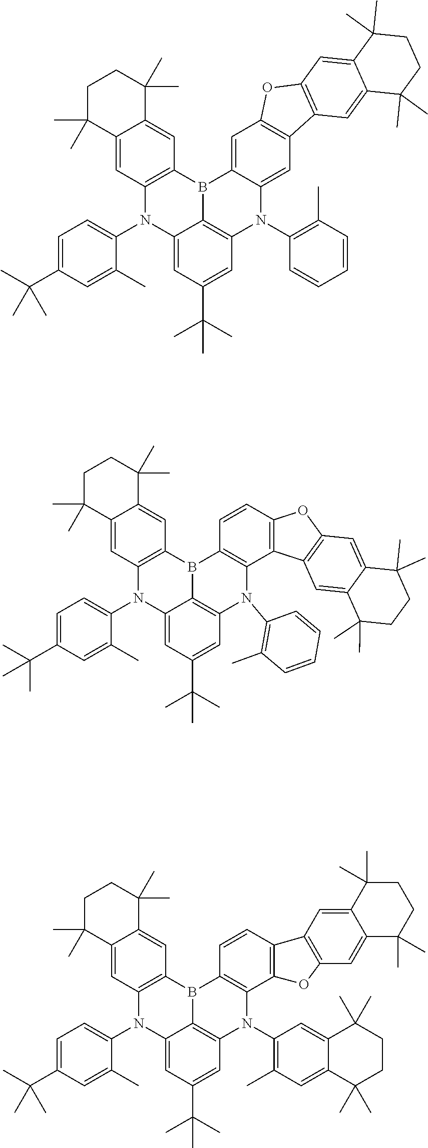

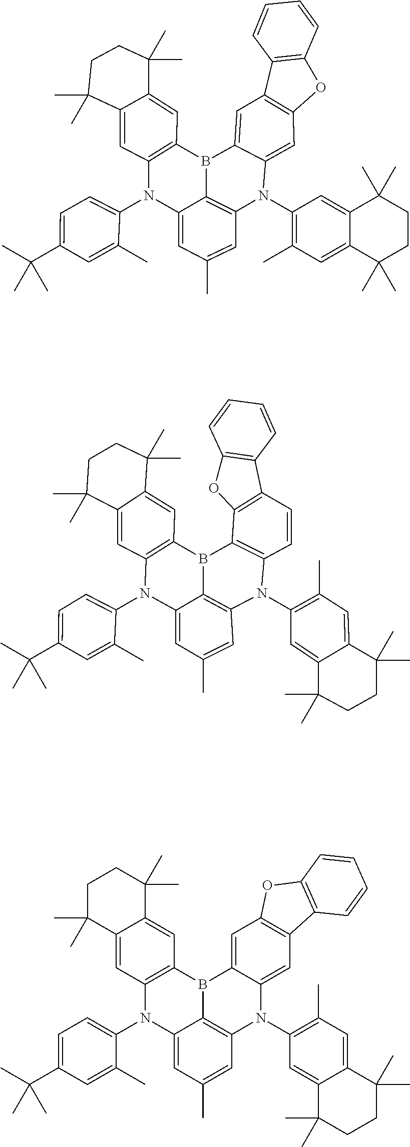

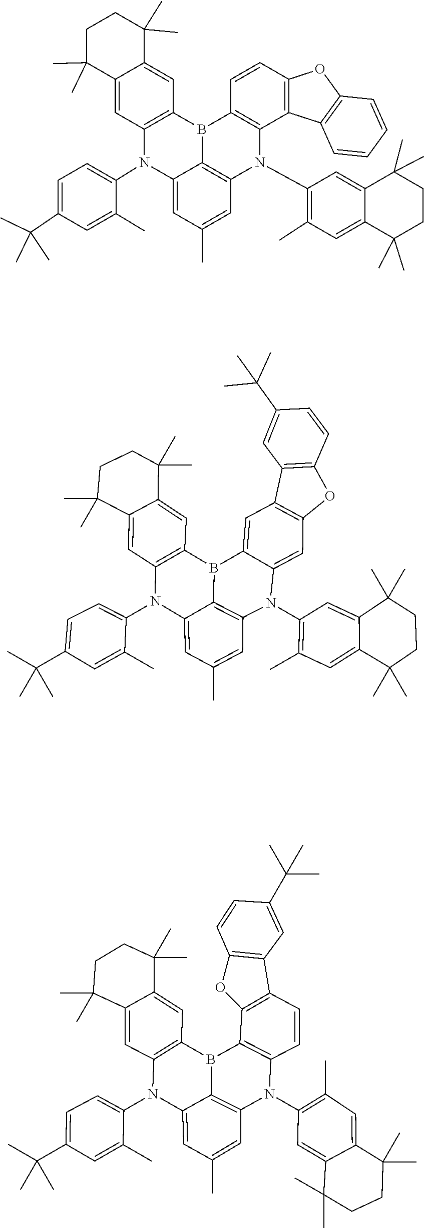

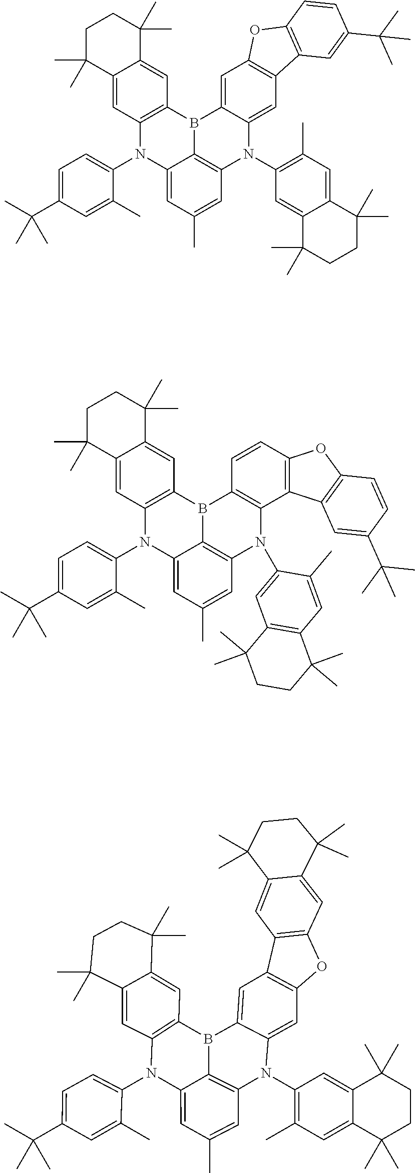

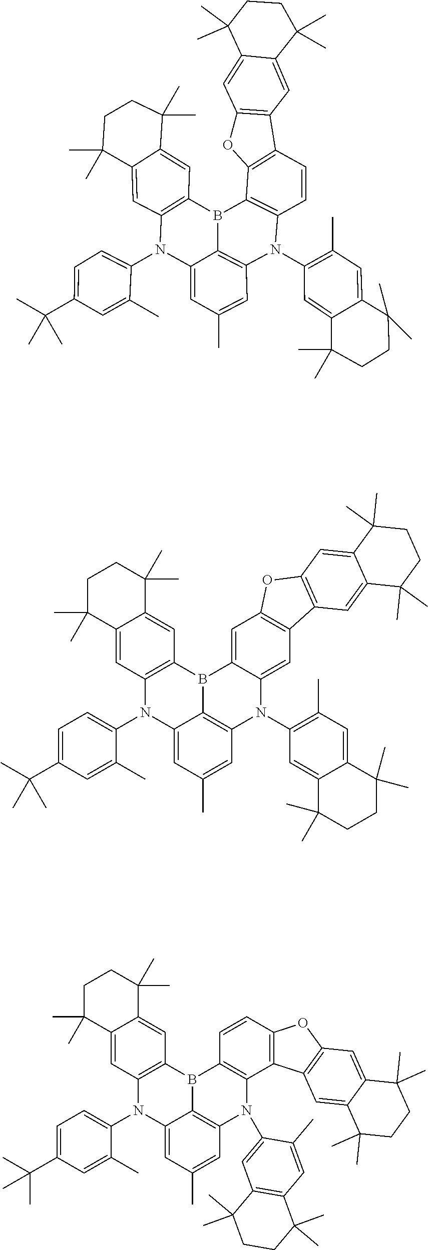

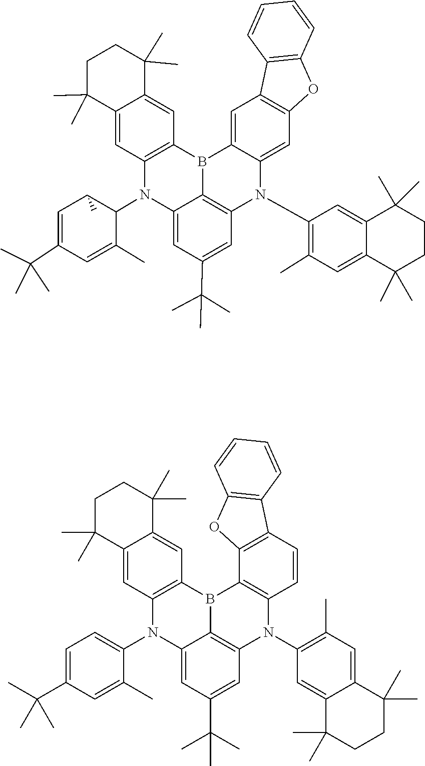

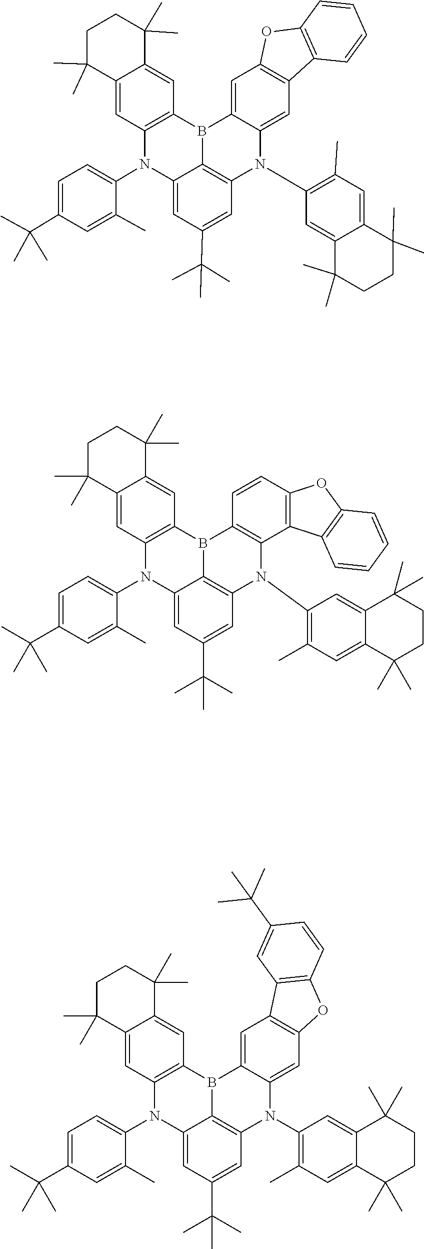

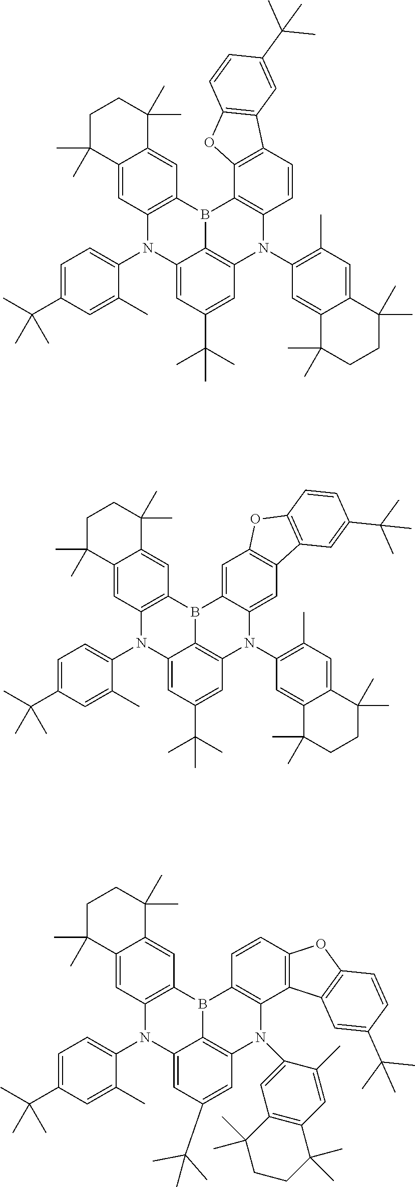

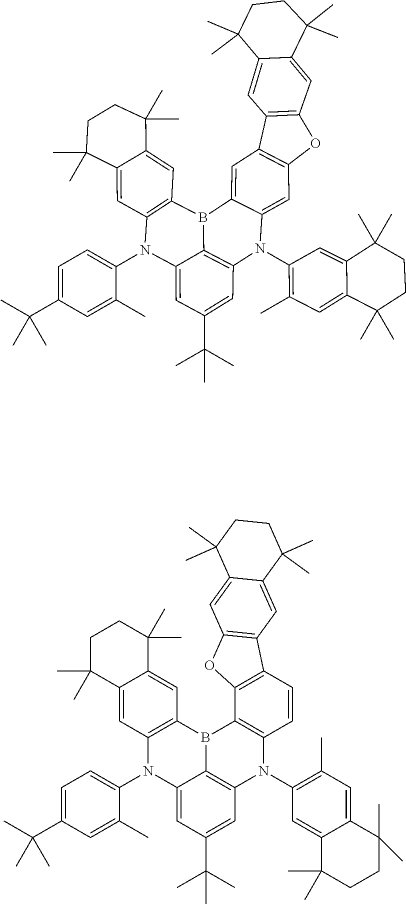 [SMILES: Cc1cc(C(C)(C)C)ccc1N1c2cc3c(cc2B2c4cc5c(cc4N(c4cc6c(cc4C)C(C)(C)CCC6(C)C)c4cc(C(C)(C)C)cc1c42)oc1cc2c(cc15)C(C)(C)CCC2(C)C)C(C)(C)CCC3(C)C ; Cc1cc(C(C)(C)C)ccc1N1c2cc3c(cc2B2c4c1cc(C(C)(C)C)cc4N(c1cc4c(cc1C)C(C)(C)CCC4(C)C)c1ccc4c(oc5cc6c(cc54)C(C)(C)CCC6(C)C)c12)C(C)(C)CCC3(C)C]

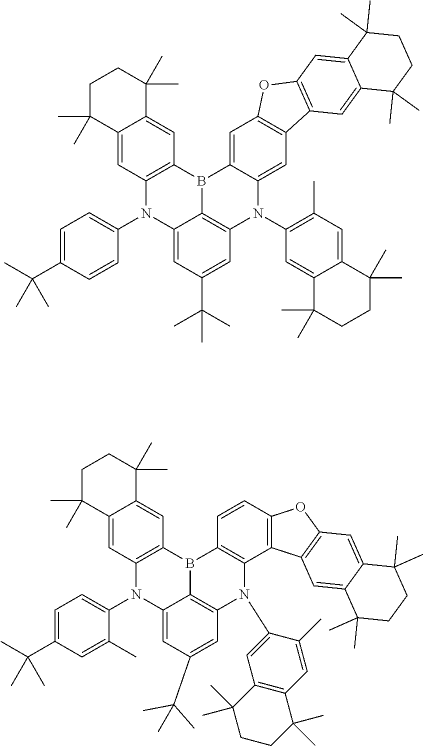

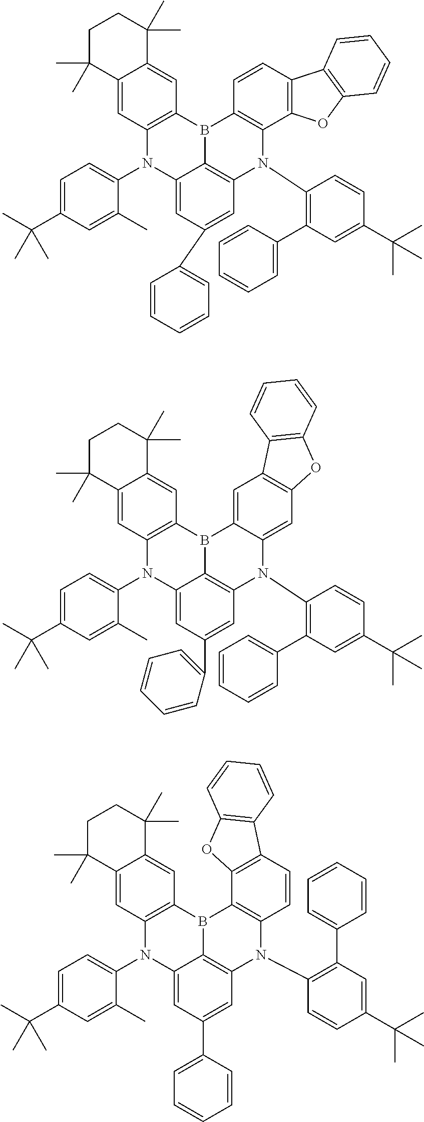

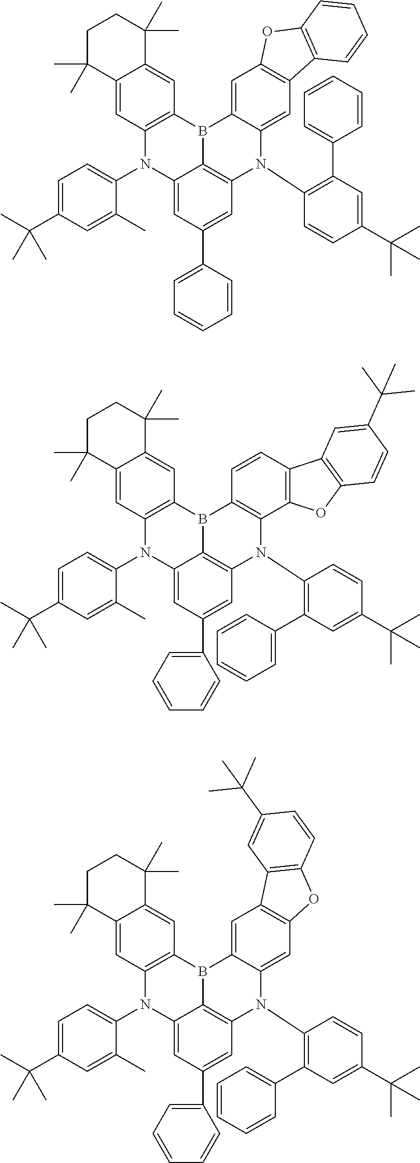

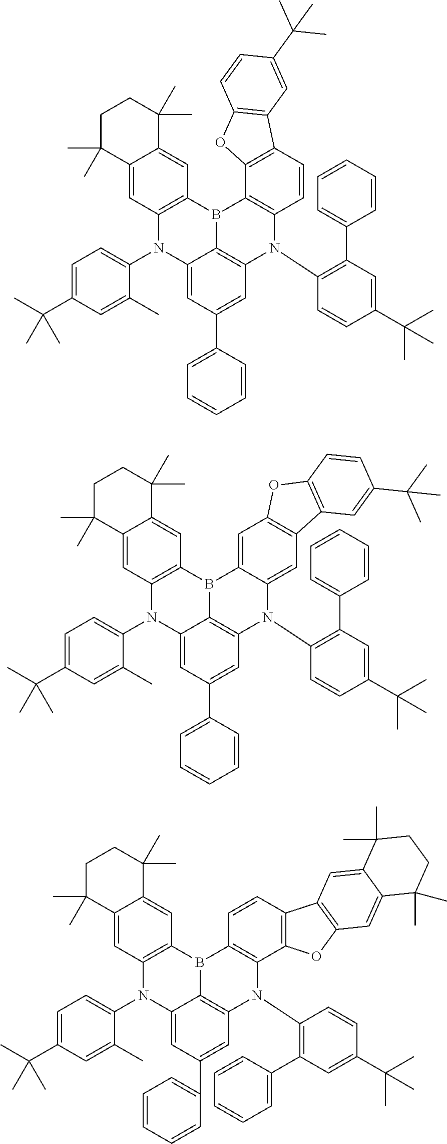

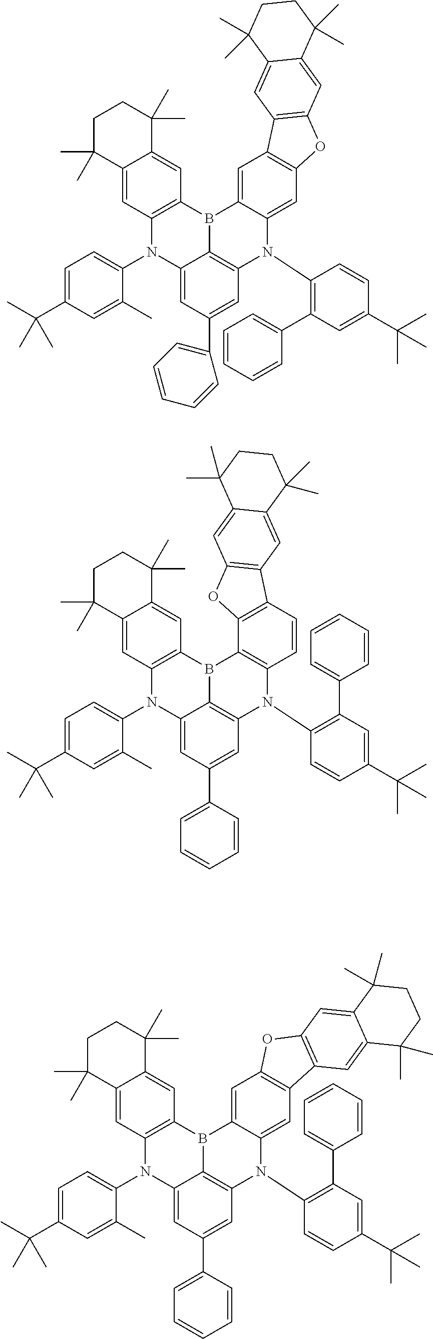

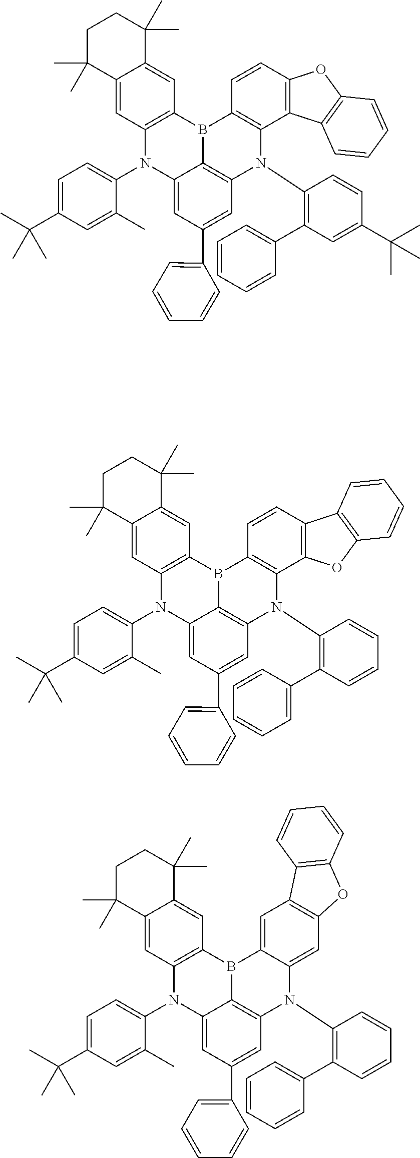

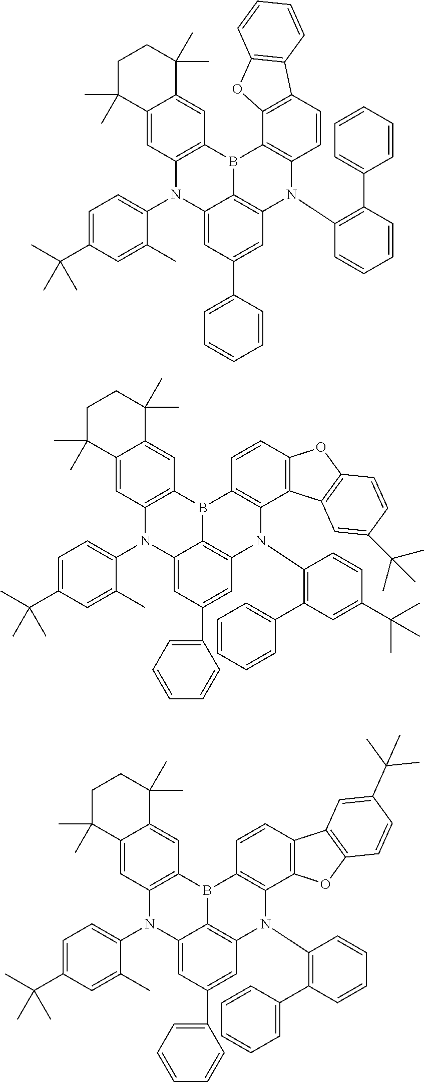

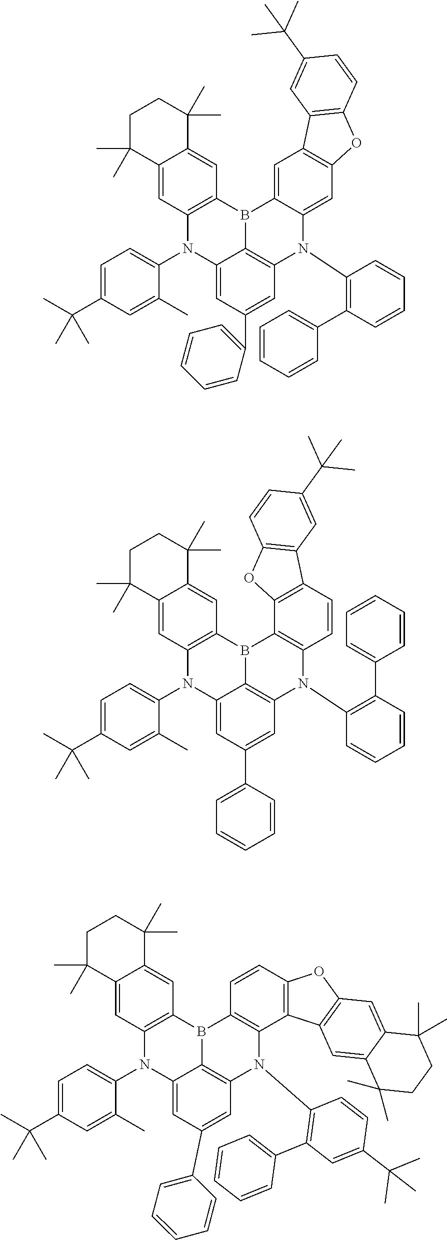 [SMILES: Cc1cc(C(C)(C)C)ccc1N1c2cc3c(cc2B2c4cc5c(cc4N(c4ccccc4-c4ccccc4)c4cc(-c6ccccc6)cc1c42)oc1ccc(C(C)(C)C)cc15)C(C)(C)CCC3(C)C ; Cc1cc(C(C)(C)C)ccc1N1c2cc3c(cc2B2c4c1cc(-c1ccccc1)cc4N(c1ccccc1-c1ccccc1)c1ccc4c(oc5ccc(C(C)(C)C)cc54)c12)C(C)(C)CCC3(C)C ; Cc1cc(C(C)(C)C)ccc1N1c2cc3c(cc2B2c4ccc5oc6cc7c(cc6c5c4N(c4ccc(C(C)(C)C)cc4-c4ccccc4)c4cc(-c5ccccc5)cc1c42)C(C)(C)CCC7(C)C)C(C)(C)CCC3(C)C]

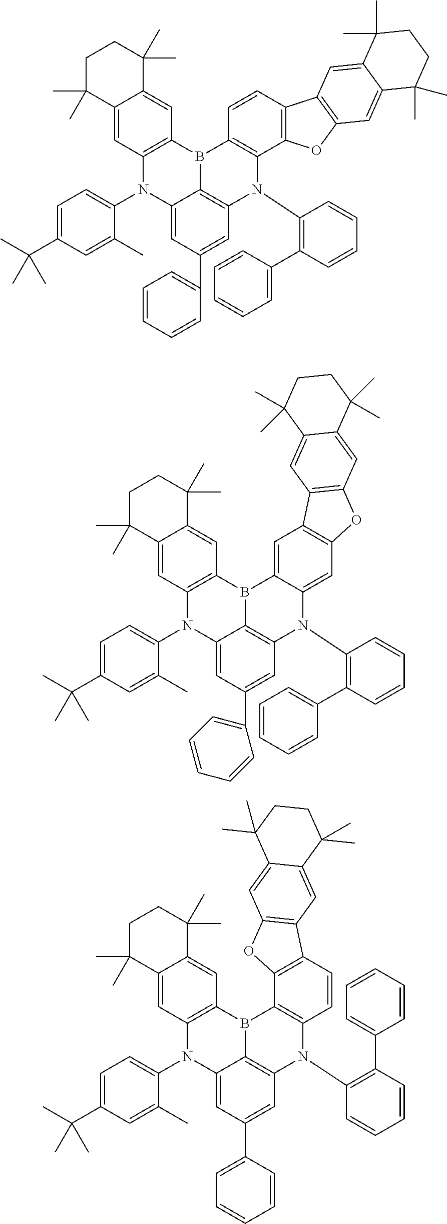

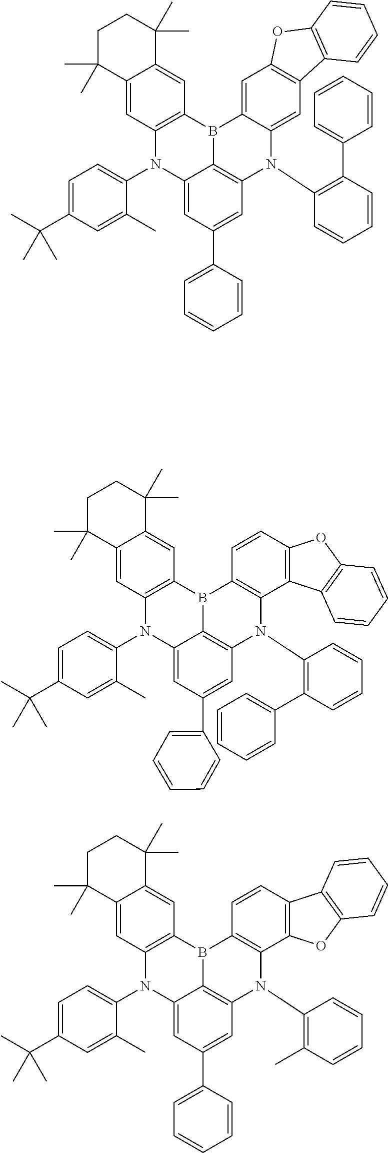

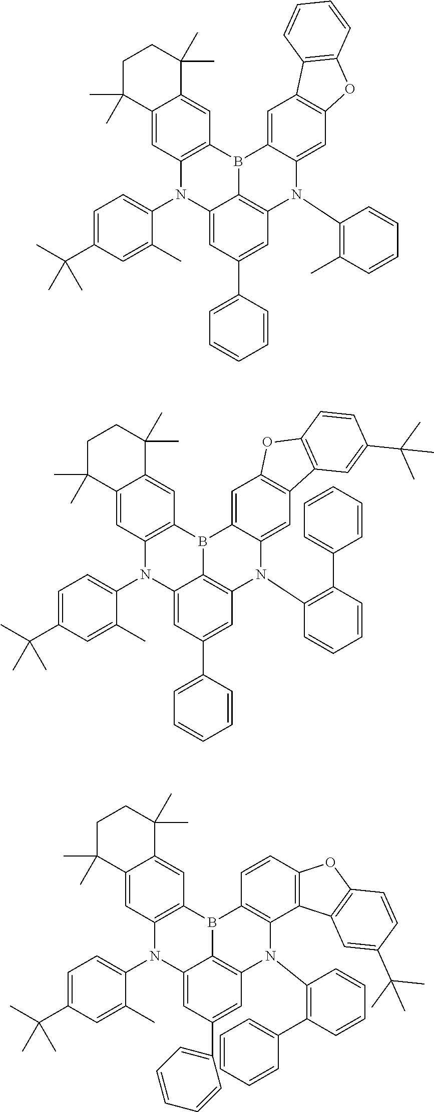

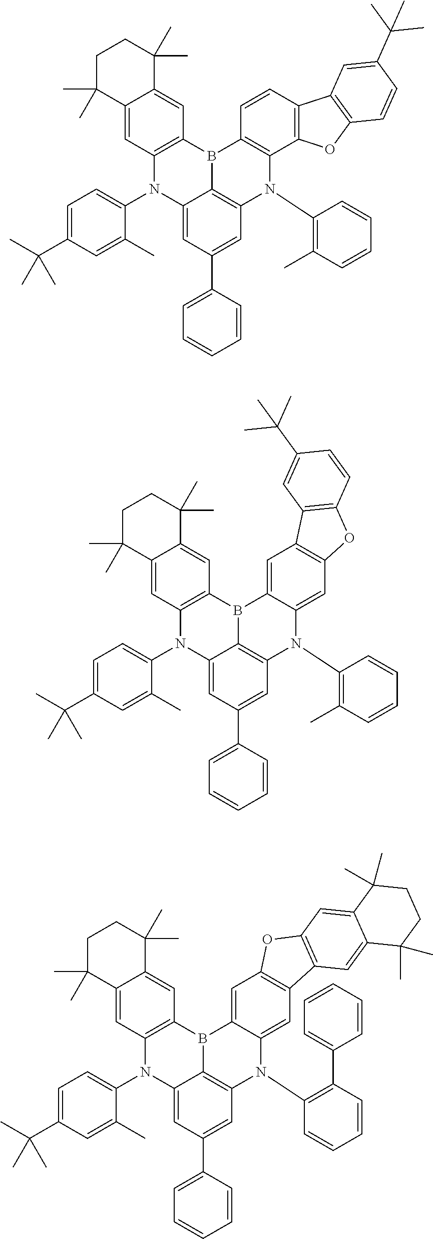

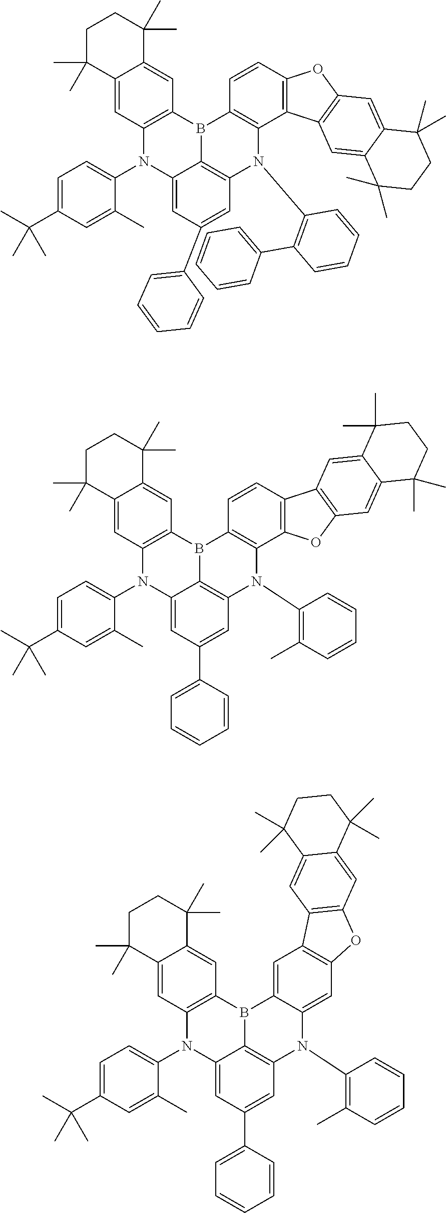

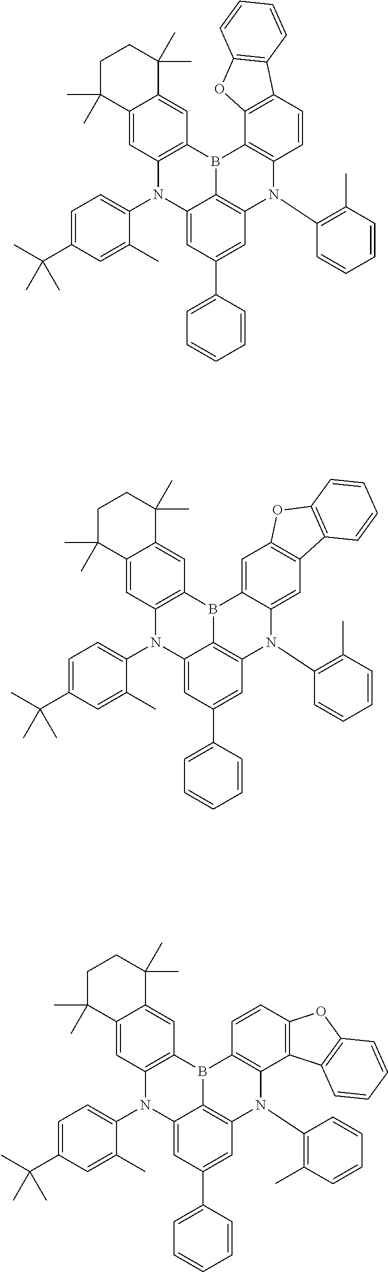 [SMILES: Cc1cc(C(C)(C)C)ccc1N1c2cc3c(cc2B2c4c1cc(-c1ccccc1)cc4N(c1ccccc1C)c1ccc4c(oc5ccccc54)c12)C(C)(C)CCC3(C)C ; Cc1cc(C(C)(C)C)ccc1N1c2cc3c(cc2B2c4cc5oc6ccccc6c5cc4N(c4ccccc4C)c4cc(-c5ccccc5)cc1c42)C(C)(C)CCC3(C)C ; Cc1cc(C(C)(C)C)ccc1N1c2cc3c(cc2B2c4ccc5oc6ccccc6c5c4N(c4ccccc4C)c4cc(-c5ccccc5)cc1c42)C(C)(C)CCC3(C)C]

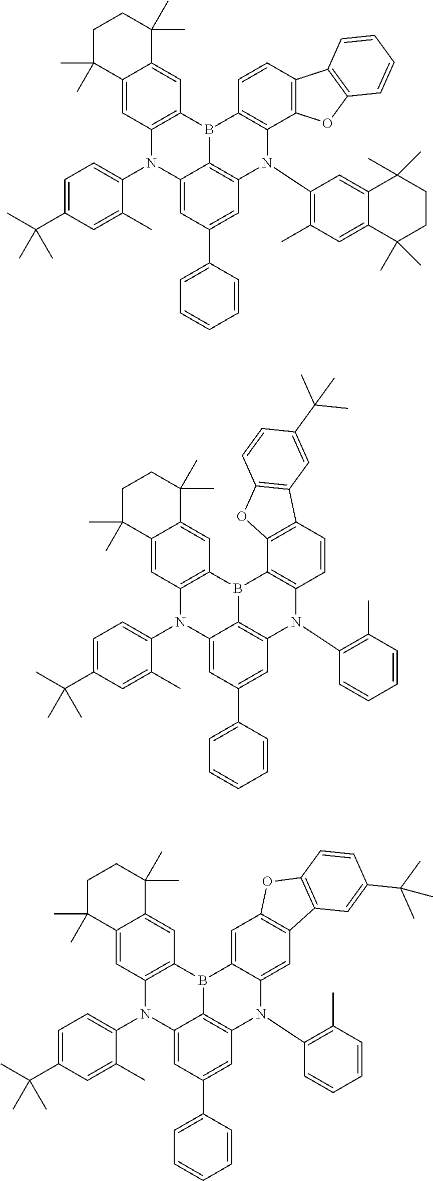 [SMILES: Cc1cc(C(C)(C)C)ccc1N1c2cc3c(cc2B2c4ccc5c(oc6ccccc65)c4N(c4cc5c(cc4C)C(C)(C)CCC5(C)C)c4cc(-c5ccccc5)cc1c42)C(C)(C)CCC3(C)C ; Cc1cc(C(C)(C)C)ccc1N1c2cc3c(cc2B2c4c1cc(-c1ccccc1)cc4N(c1ccccc1C)c1ccc4c(oc5ccc(C(C)(C)C)cc54)c12)C(C)(C)CCC3(C)C ; Cc1cc(C(C)(C)C)ccc1N1c2cc3c(cc2B2c4cc5oc6ccc(C(C)(C)C)cc6c5cc4N(c4ccccc4C)c4cc(-c5ccccc5)cc1c42)C(C)(C)CCC3(C)C]

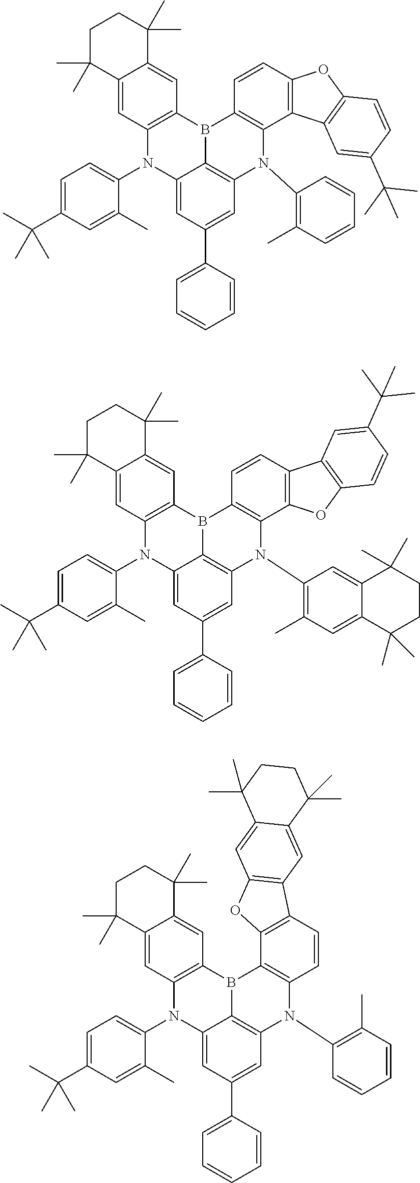

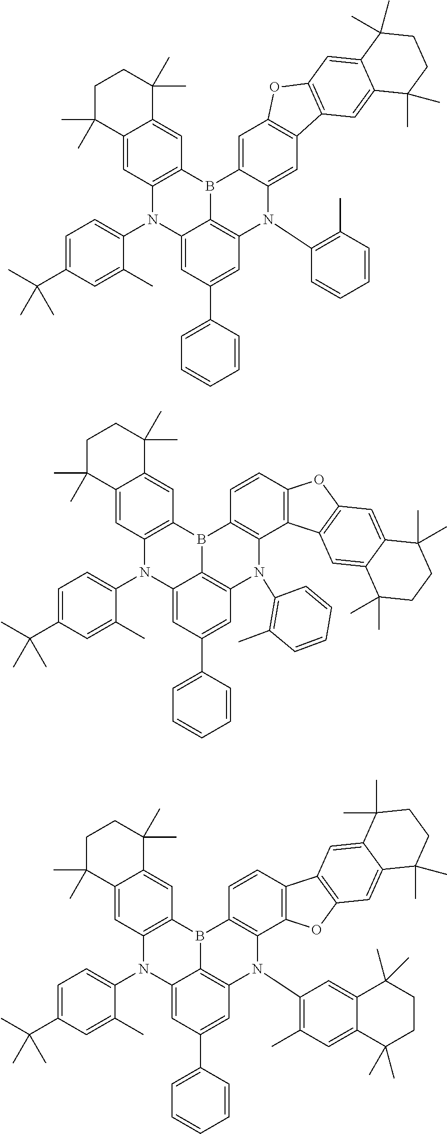

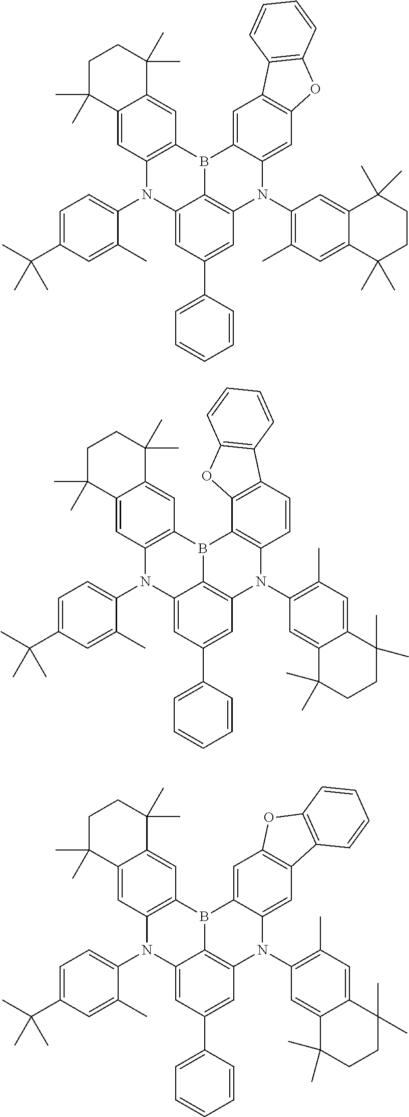

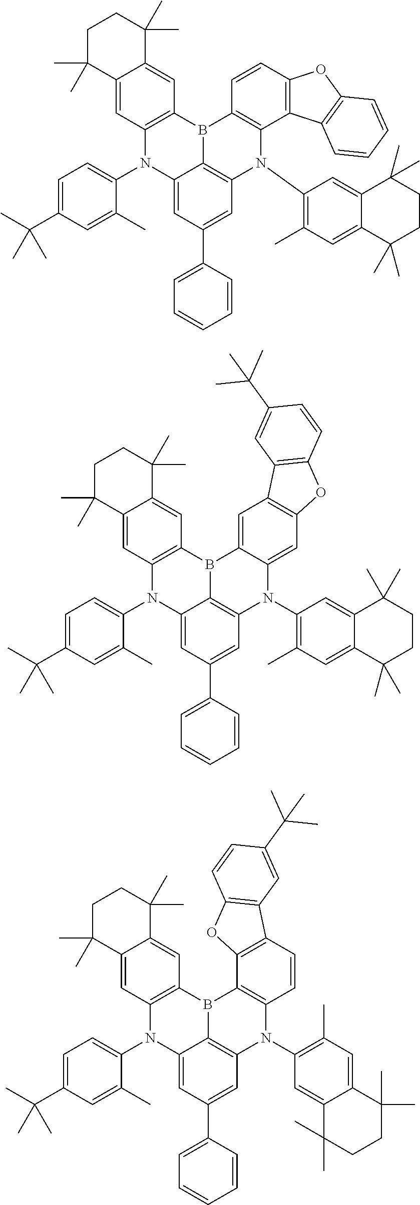

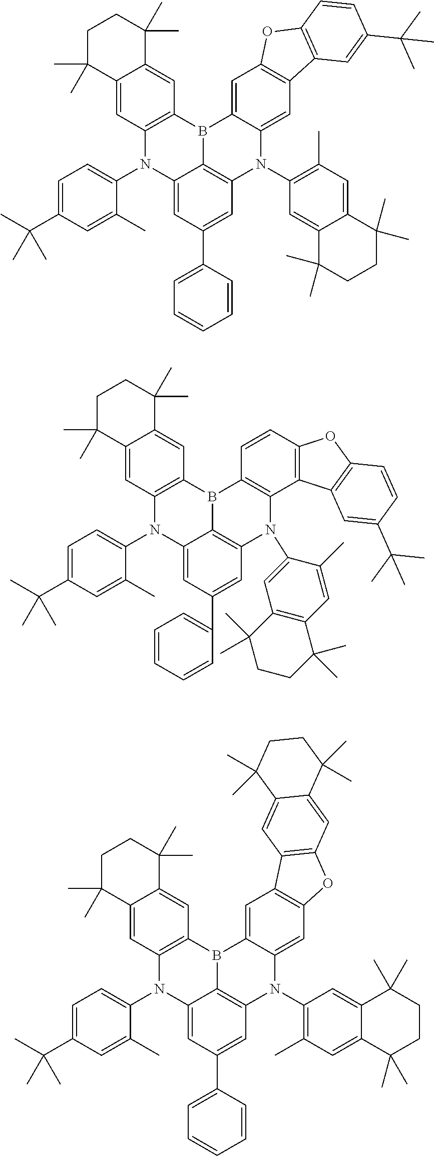

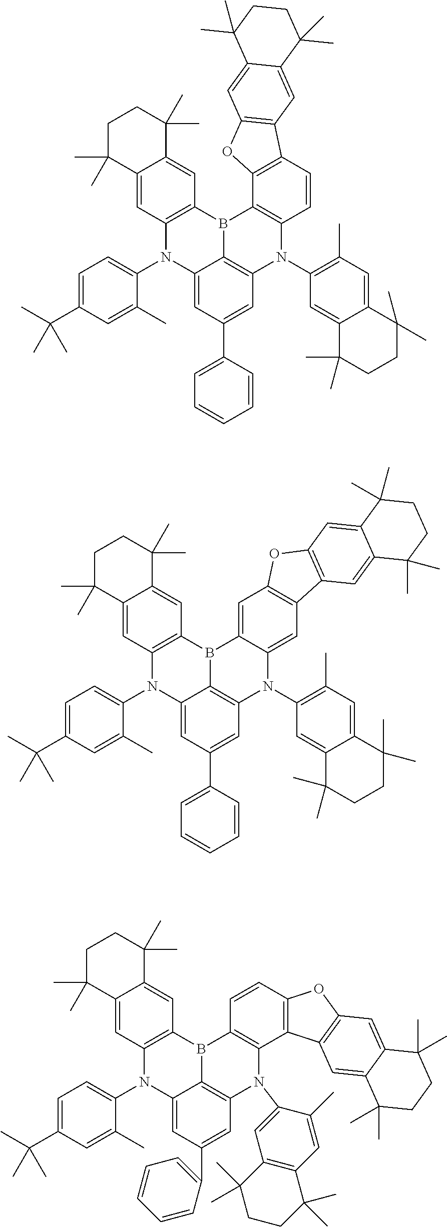

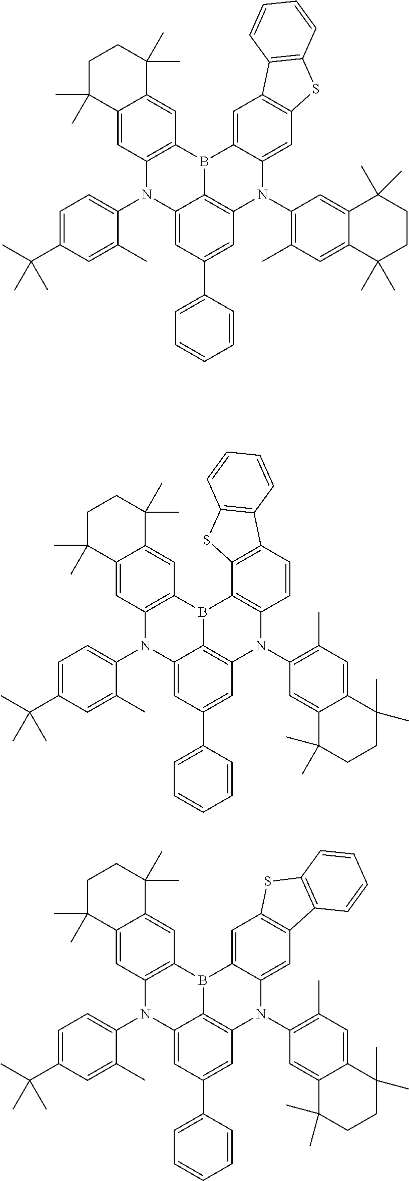

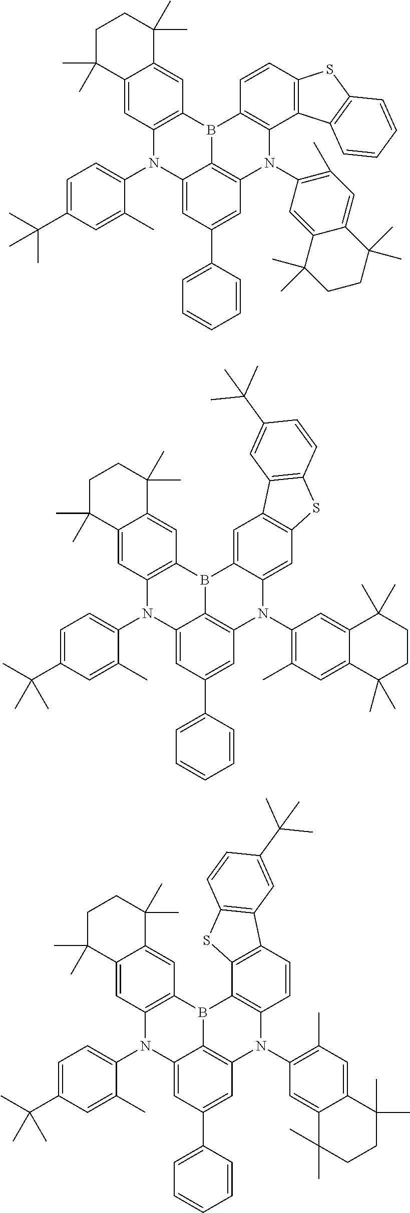

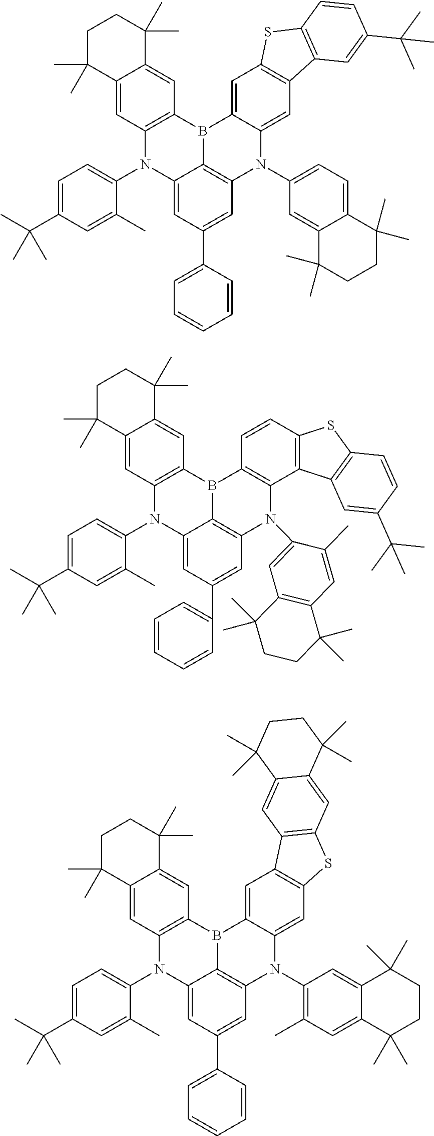

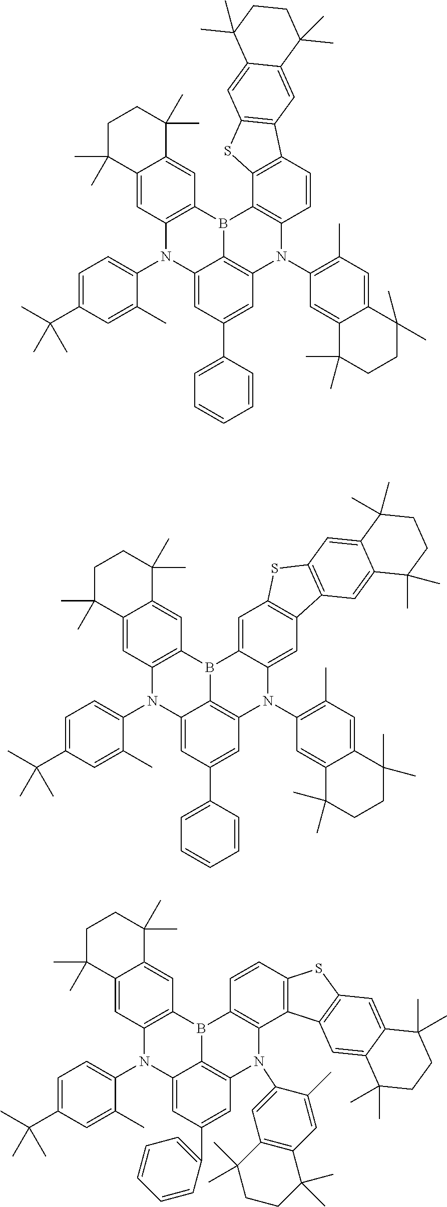

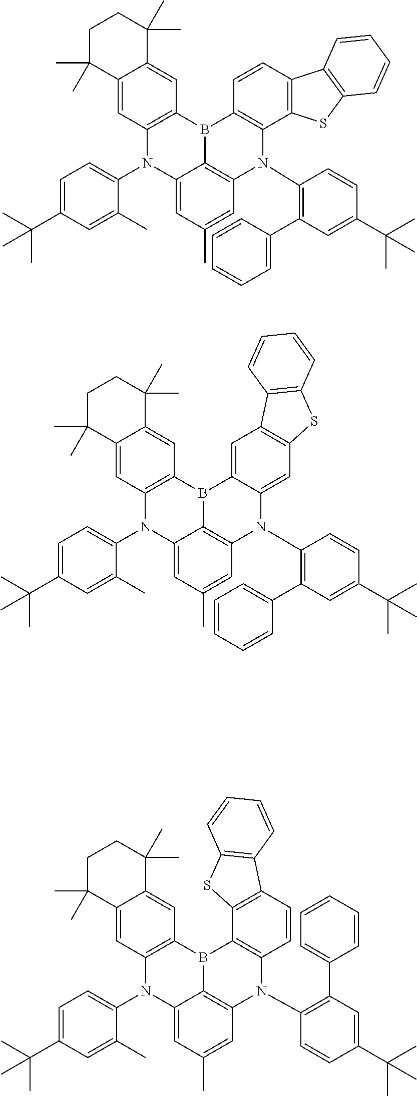

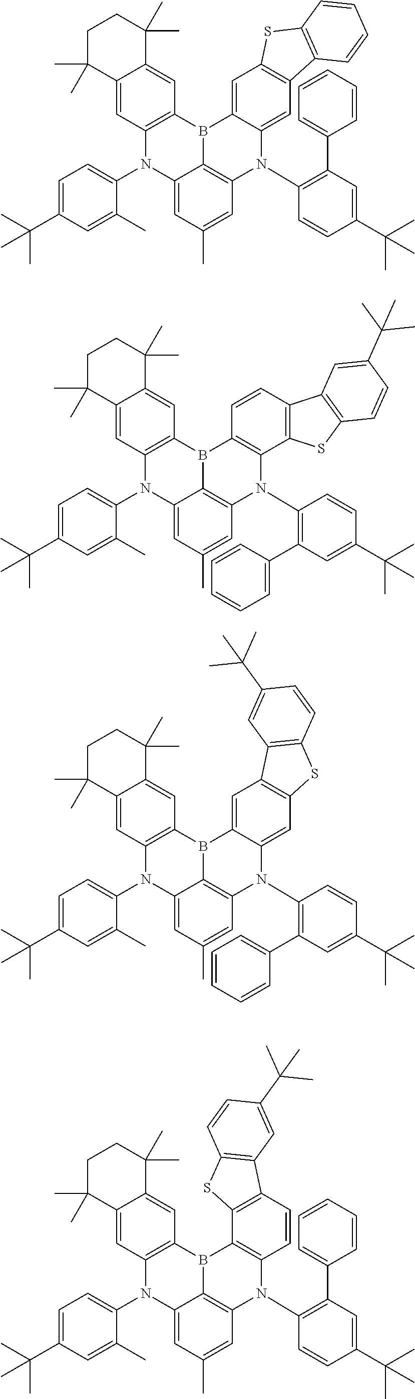

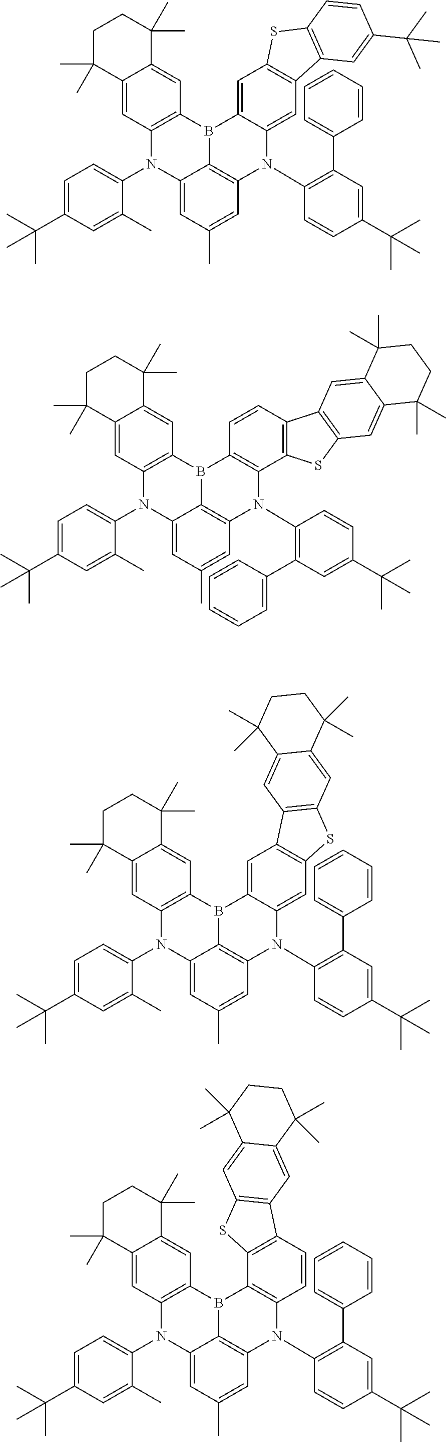

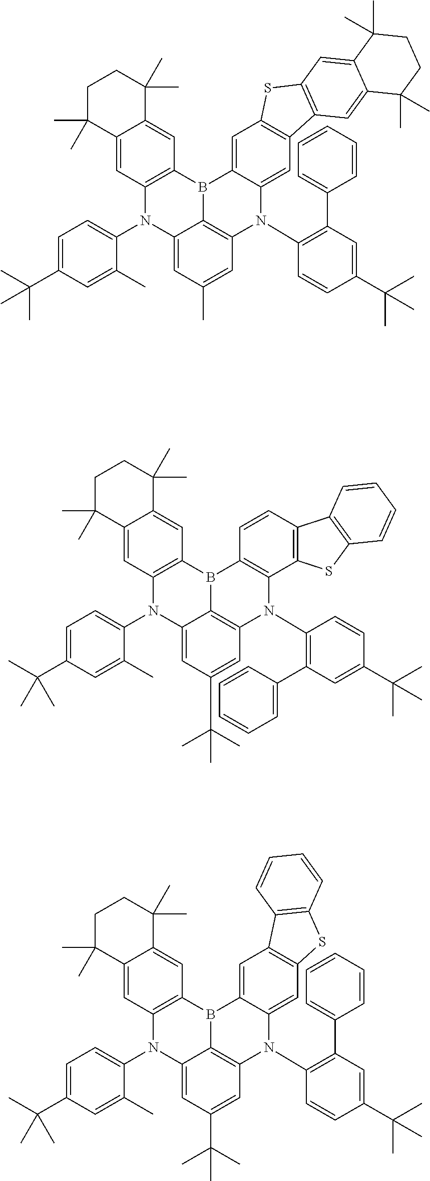

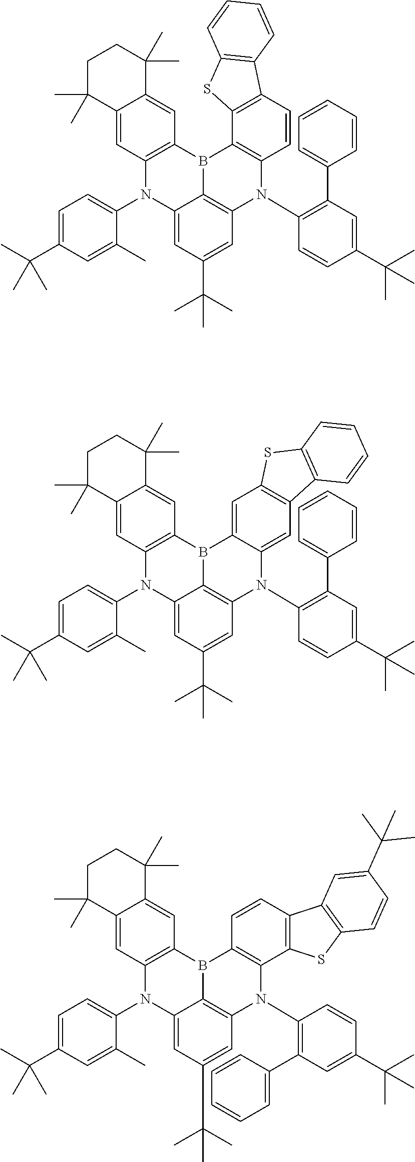

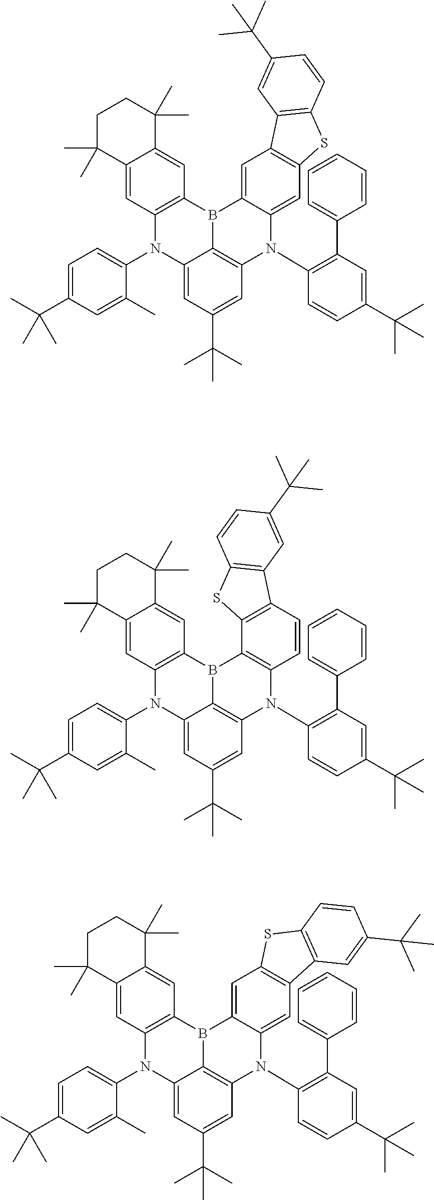

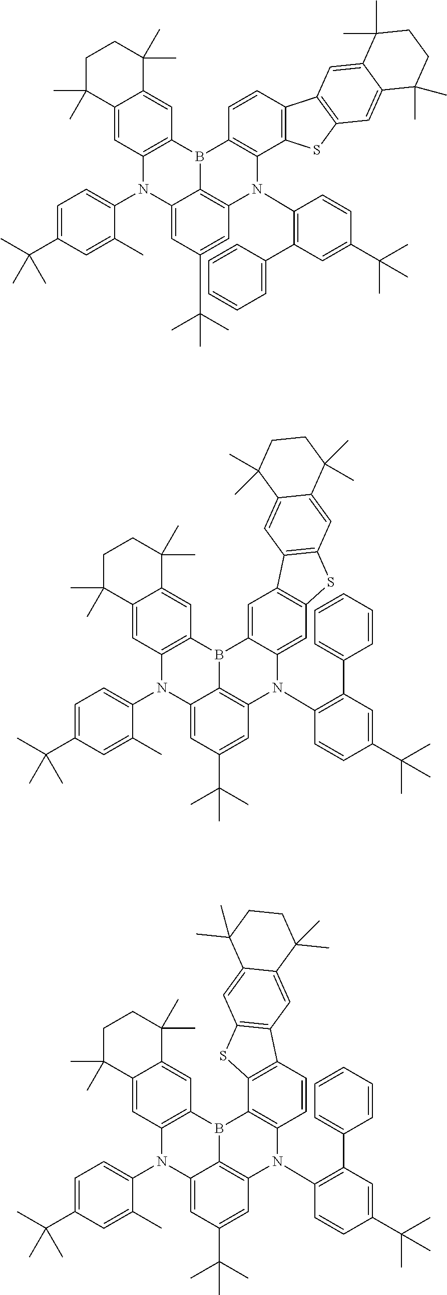

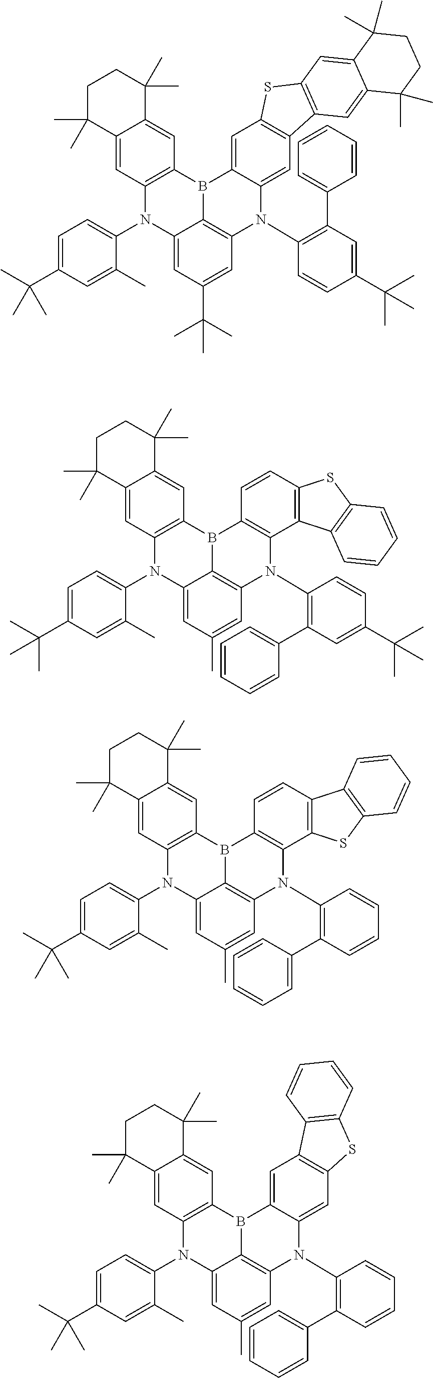

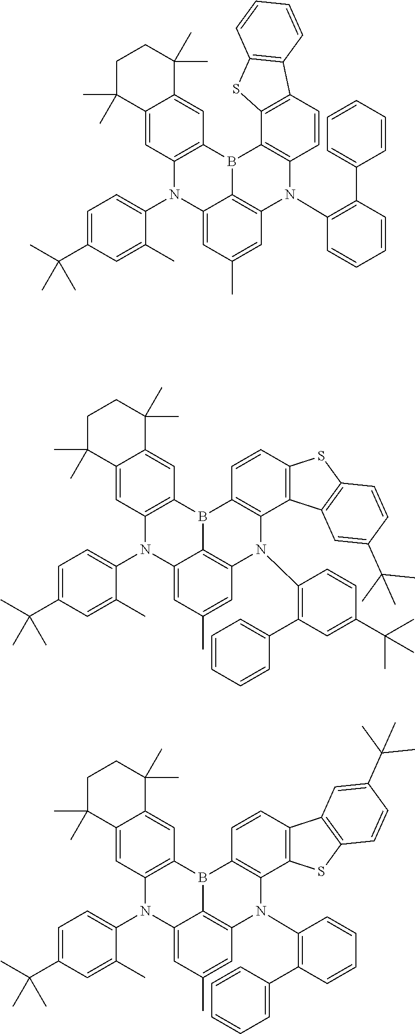

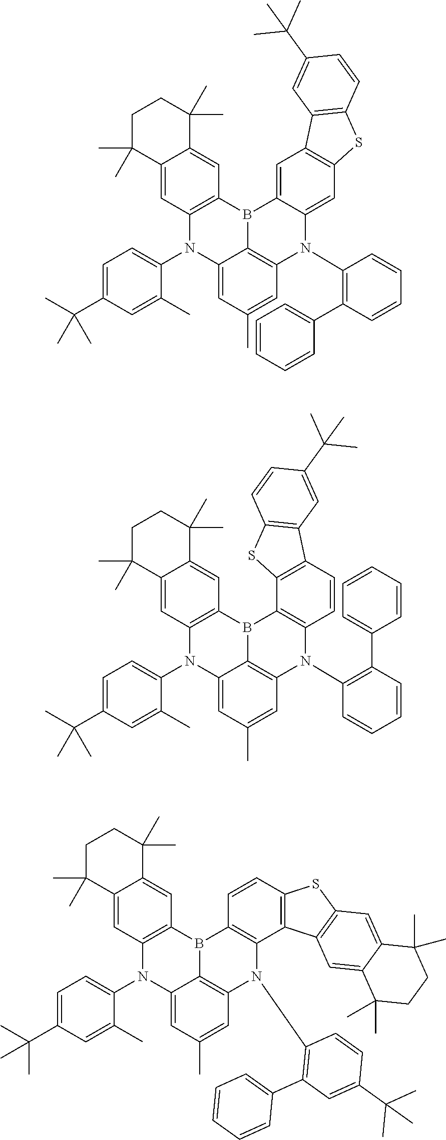 [SMILES: Cc1cc2c3c(c1)N(c1ccccc1-c1ccccc1)c1cc4sc5ccc(C(C)(C)C)cc5c4cc1B3c1cc3c(cc1N2c1ccc(C(C)(C)C)cc1C)C(C)(C)CCC3(C)C ; Cc1cc2c3c(c1)N(c1ccccc1-c1ccccc1)c1ccc4c(sc5ccc(C(C)(C)C)cc54)c1B3c1cc3c(cc1N2c1ccc(C(C)(C)C)cc1C)C(C)(C)CCC3(C)C ; Cc1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1ccc(C(C)(C)C)cc1C)C(C)(C)CCC3(C)C]

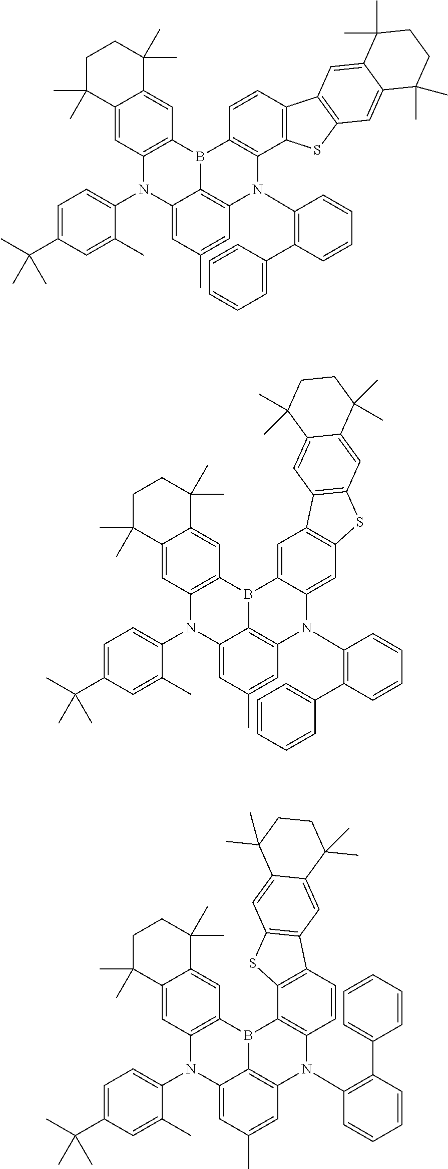

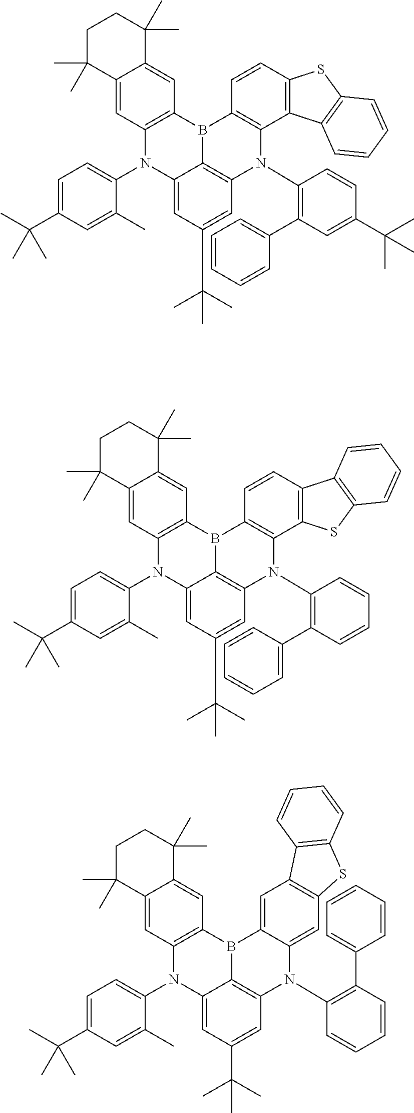

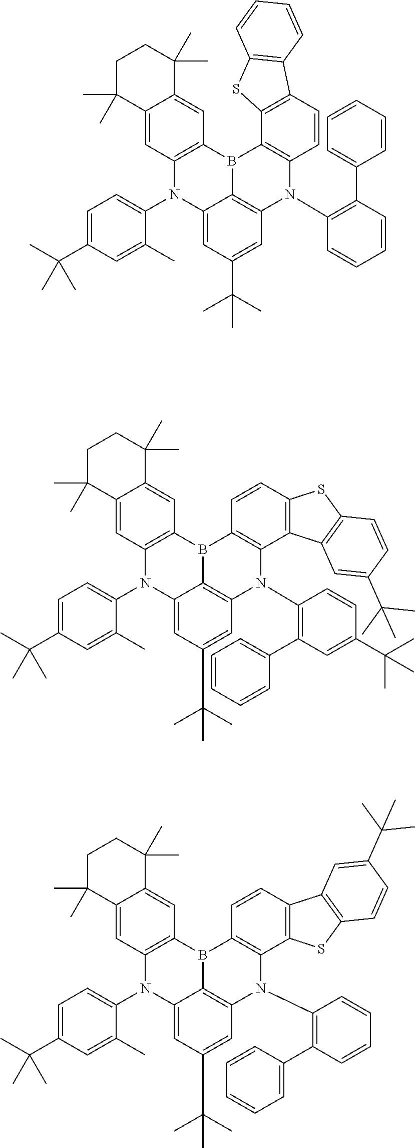

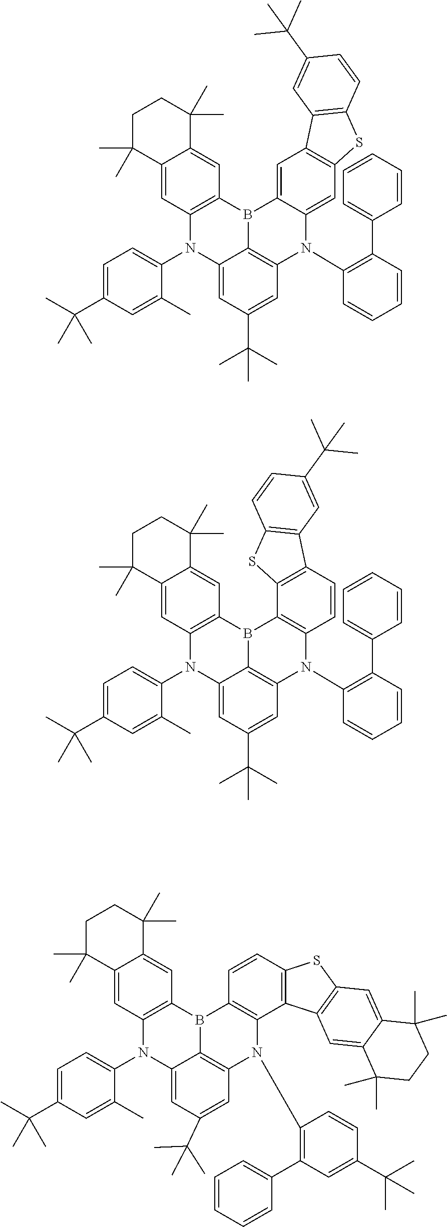 [SMILES: Cc1cc(C(C)(C)C)ccc1N1c2cc3c(cc2B2c4cc5c(cc4N(c4ccccc4-c4ccccc4)c4cc(C(C)(C)C)cc1c42)sc1ccc(C(C)(C)C)cc15)C(C)(C)CCC3(C)C ; Cc1cc(C(C)(C)C)ccc1N1c2cc3c(cc2B2c4c1cc(C(C)(C)C)cc4N(c1ccccc1-c1ccccc1)c1ccc4c(sc5ccc(C(C)(C)C)cc54)c12)C(C)(C)CCC3(C)C ; Cc1cc(C(C)(C)C)ccc1N1c2cc3c(cc2B2c4ccc5sc6cc7c(cc6c5c4N(c4ccc(C(C)(C)C)cc4-c4ccccc4)c4cc(C(C)(C)C)cc1c42)C(C)(C)CCC7(C)C)C(C)(C)CCC3(C)C]

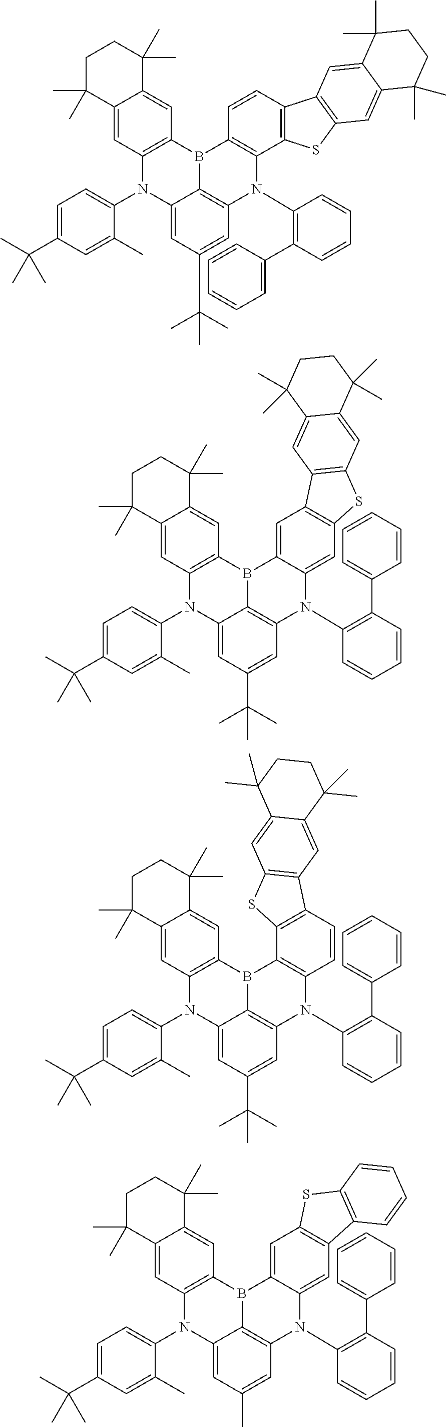

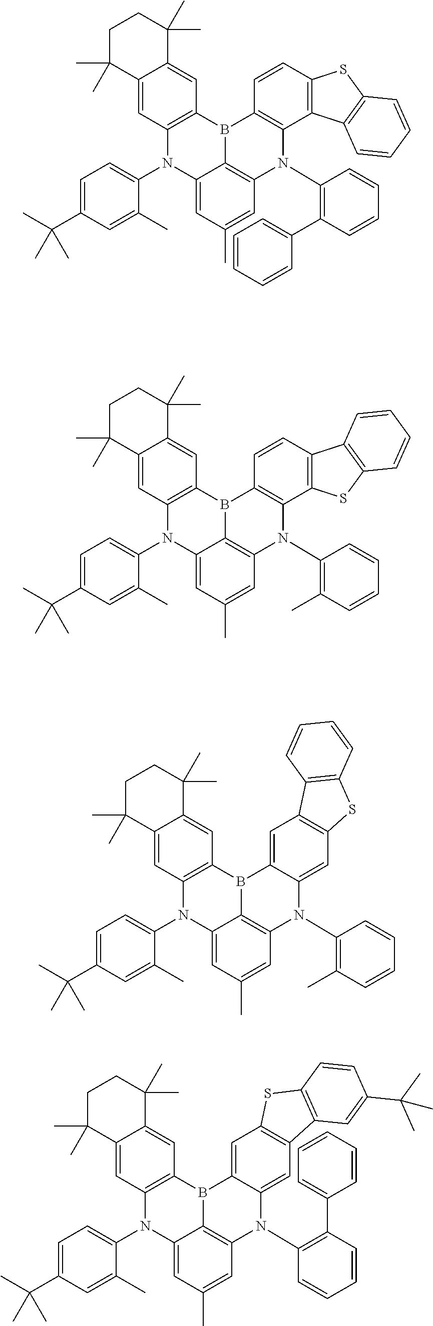 [SMILES: Cc1cc2c3c(c1)N(c1ccccc1-c1ccccc1)c1c(ccc4sc5ccccc5c14)B3c1cc3c(cc1N2c1ccc(C(C)(C)C)cc1C)C(C)(C)CCC3(C)C ; Cc1cc2c3c(c1)N(c1ccccc1C)c1c(ccc4c1sc1ccccc14)B3c1cc3c(cc1N2c1ccc(C(C)(C)C)cc1C)C(C)(C)CCC3(C)C ; Cc1cc2c3c(c1)N(c1ccccc1C)c1cc4sc5ccccc5c4cc1B3c1cc3c(cc1N2c1ccc(C(C)(C)C)cc1C)C(C)(C)CCC3(C)C ; Cc1cc2c3c(c1)N(c1ccccc1-c1ccccc1)c1cc4c(cc1B3c1cc3c(cc1N2c1ccc(C(C)(C)C)cc1C)C(C)(C)CCC3(C)C)sc1ccc(C(C)(C)C)cc14]

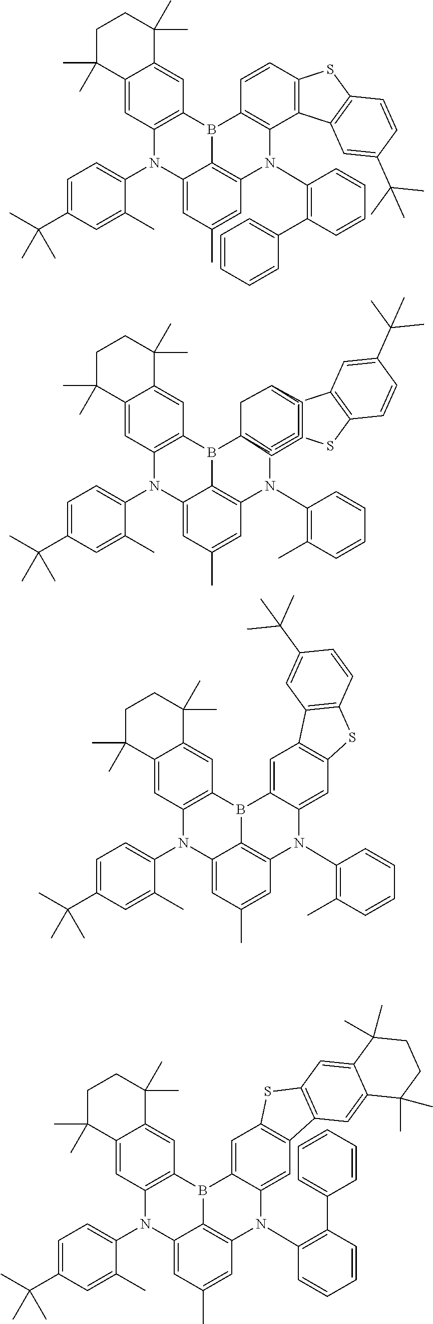

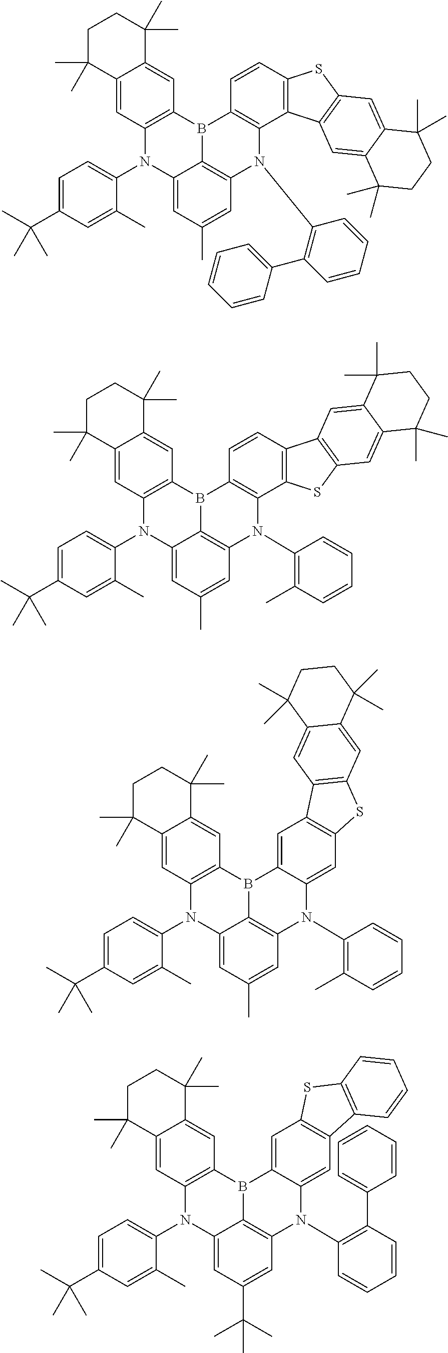

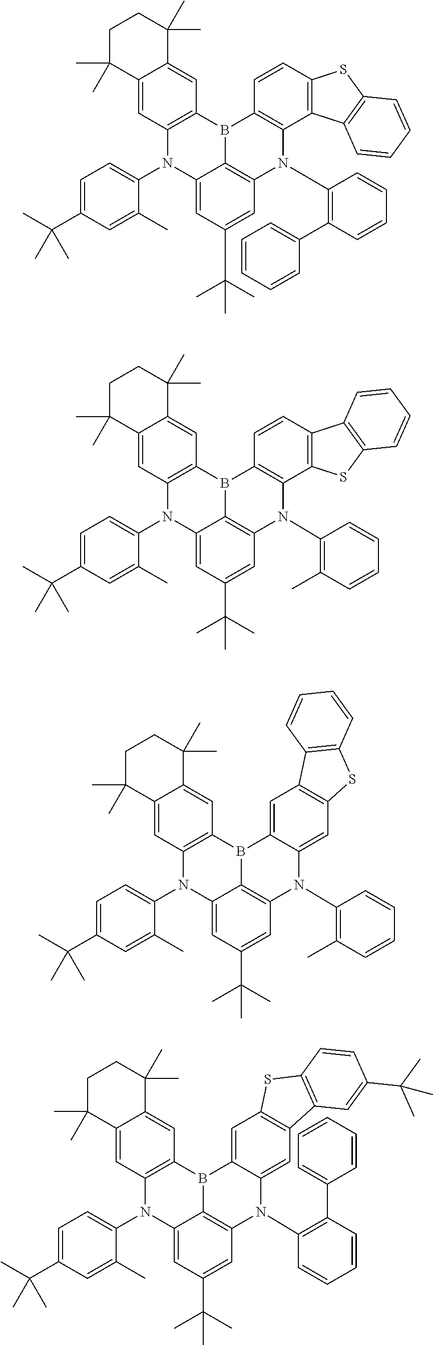 [SMILES: Cc1cc(C(C)(C)C)ccc1N1c2cc3c(cc2B2c4ccc5sc6ccccc6c5c4N(c4ccccc4-c4ccccc4)c4cc(C(C)(C)C)cc1c42)C(C)(C)CCC3(C)C ; Cc1cc(C(C)(C)C)ccc1N1c2cc3c(cc2B2c4ccc5c(sc6ccccc65)c4N(c4ccccc4C)c4cc(C(C)(C)C)cc1c42)C(C)(C)CCC3(C)C ; Cc1cc(C(C)(C)C)ccc1N1c2cc3c(cc2B2c4cc5c(cc4N(c4ccccc4C)c4cc(C(C)(C)C)cc1c42)sc1ccccc15)C(C)(C)CCC3(C)C ; Cc1cc(C(C)(C)C)ccc1N1c2cc3c(cc2B2c4cc5sc6ccc(C(C)(C)C)cc6c5cc4N(c4ccccc4-c4ccccc4)c4cc(C(C)(C)C)cc1c42)C(C)(C)CCC3(C)C]

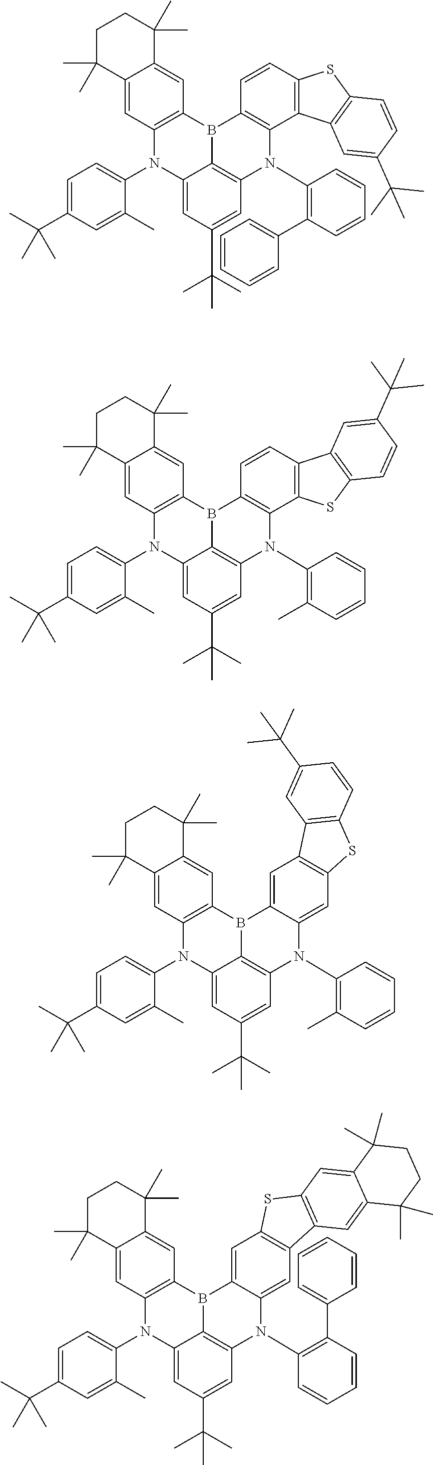

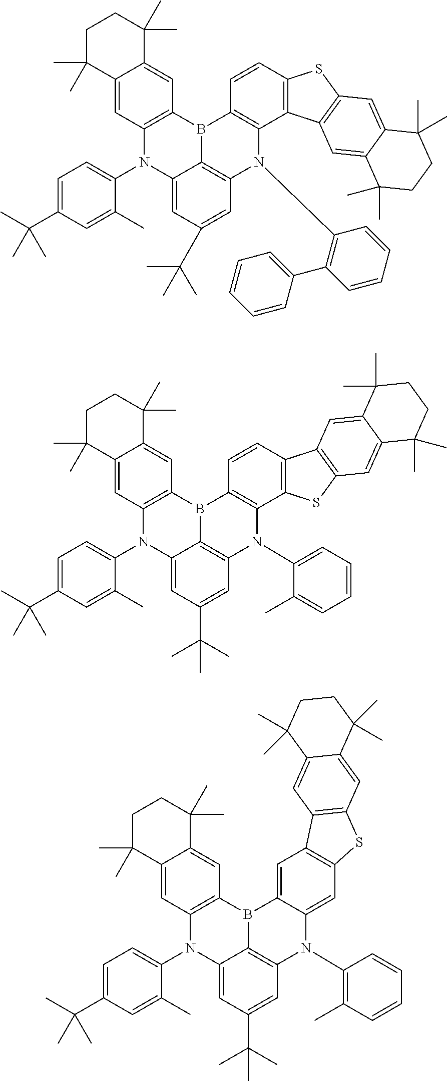

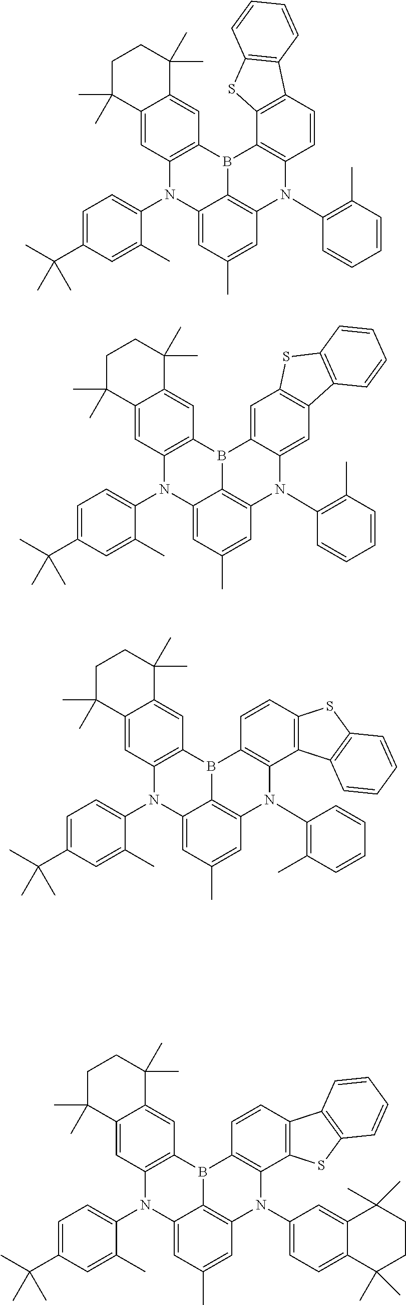 [SMILES: Cc1cc2c3c(c1)N(c1ccccc1C)c1ccc4c(sc5ccccc54)c1B3c1cc3c(cc1N2c1ccc(C(C)(C)C)cc1C)C(C)(C)CCC3(C)C ; Cc1cc2c3c(c1)N(c1ccccc1C)c1cc4c(cc1B3c1cc3c(cc1N2c1ccc(C(C)(C)C)cc1C)C(C)(C)CCC3(C)C)sc1ccccc14 ; Cc1cc2c3c(c1)N(c1ccccc1C)c1c(ccc4sc5ccccc5c14)B3c1cc3c(cc1N2c1ccc(C(C)(C)C)cc1C)C(C)(C)CCC3(C)C ; Cc1cc2c3c(c1)N(c1ccc4c(c1)C(C)(C)CCC4(C)C)c1c(ccc4c1sc1ccccc14)B3c1cc3c(cc1N2c1ccc(C(C)(C)C)cc1C)C(C)(C)CCC3(C)C]

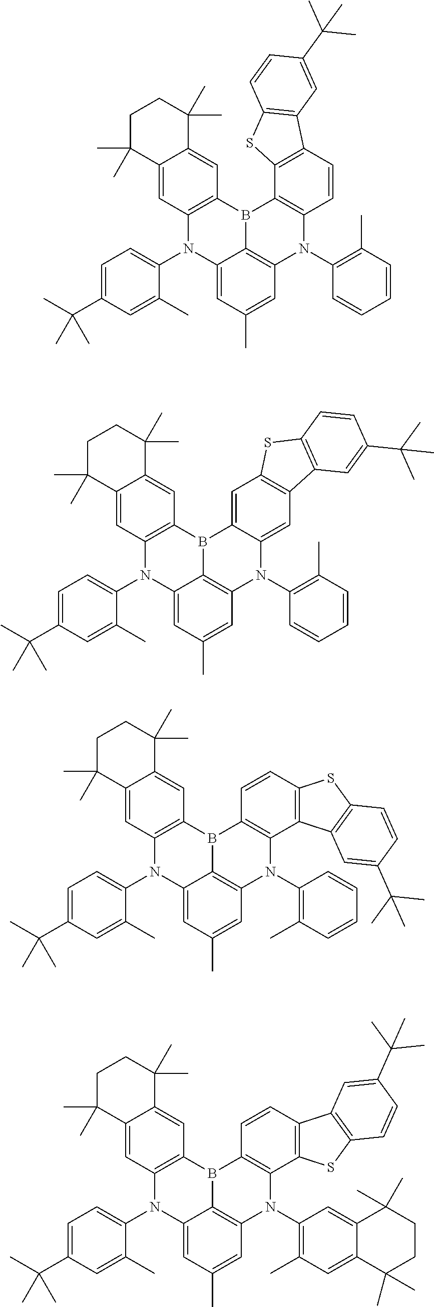

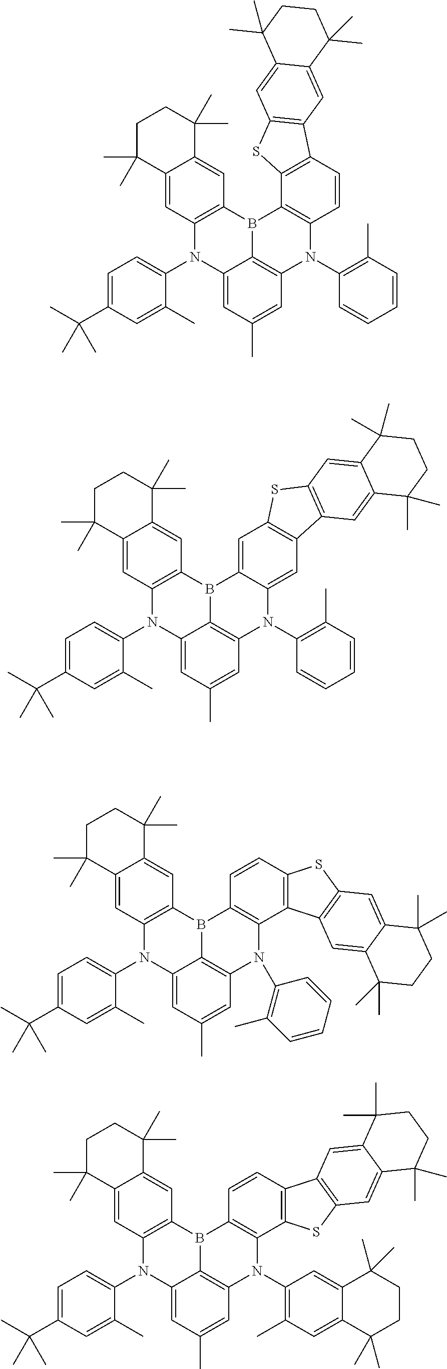

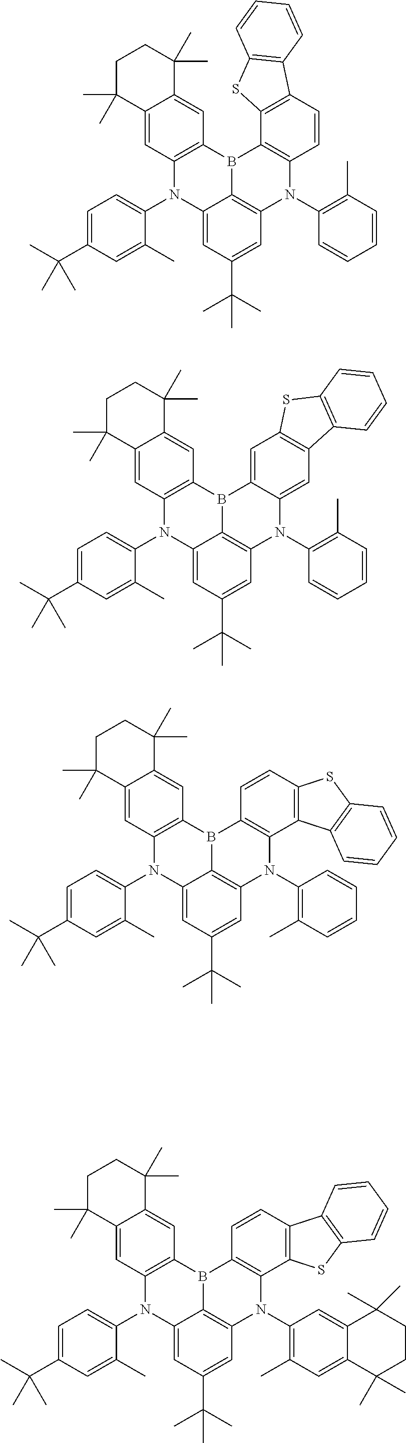 [SMILES: Cc1cc(C(C)(C)C)ccc1N1c2cc3c(cc2B2c4c1cc(C(C)(C)C)cc4N(c1ccccc1C)c1ccc4c(sc5ccccc54)c12)C(C)(C)CCC3(C)C ; Cc1cc(C(C)(C)C)ccc1N1c2cc3c(cc2B2c4cc5sc6ccccc6c5cc4N(c4ccccc4C)c4cc(C(C)(C)C)cc1c42)C(C)(C)CCC3(C)C ; Cc1cc(C(C)(C)C)ccc1N1c2cc3c(cc2B2c4ccc5sc6ccccc6c5c4N(c4ccccc4C)c4cc(C(C)(C)C)cc1c42)C(C)(C)CCC3(C)C ; Cc1cc(C(C)(C)C)ccc1N1c2cc3c(cc2B2c4ccc5c(sc6ccccc65)c4N(c4cc5c(cc4C)C(C)(C)CCC5(C)C)c4cc(C(C)(C)C)cc1c42)C(C)(C)CCC3(C)C]

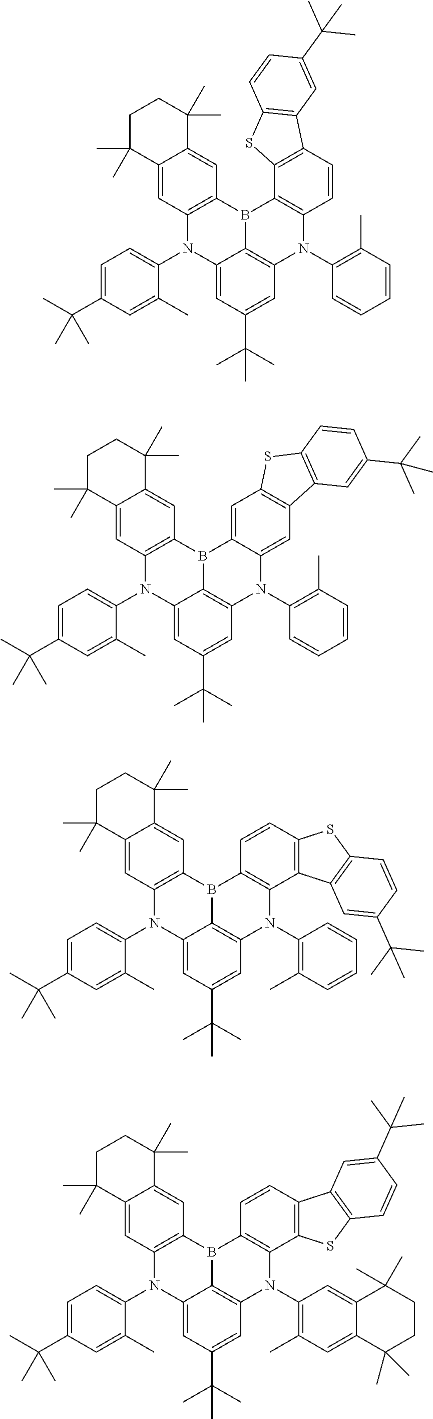

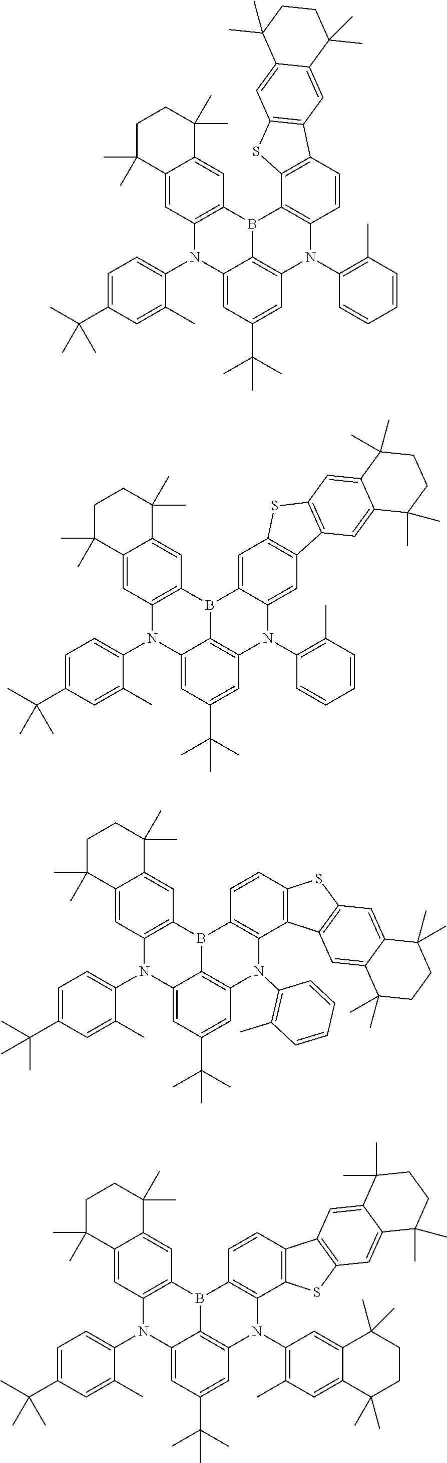

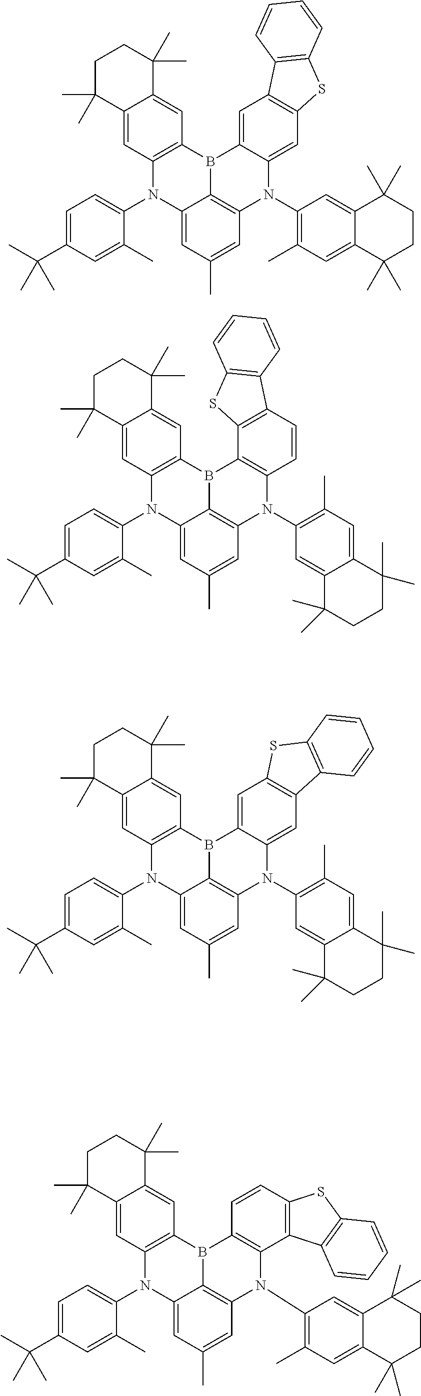

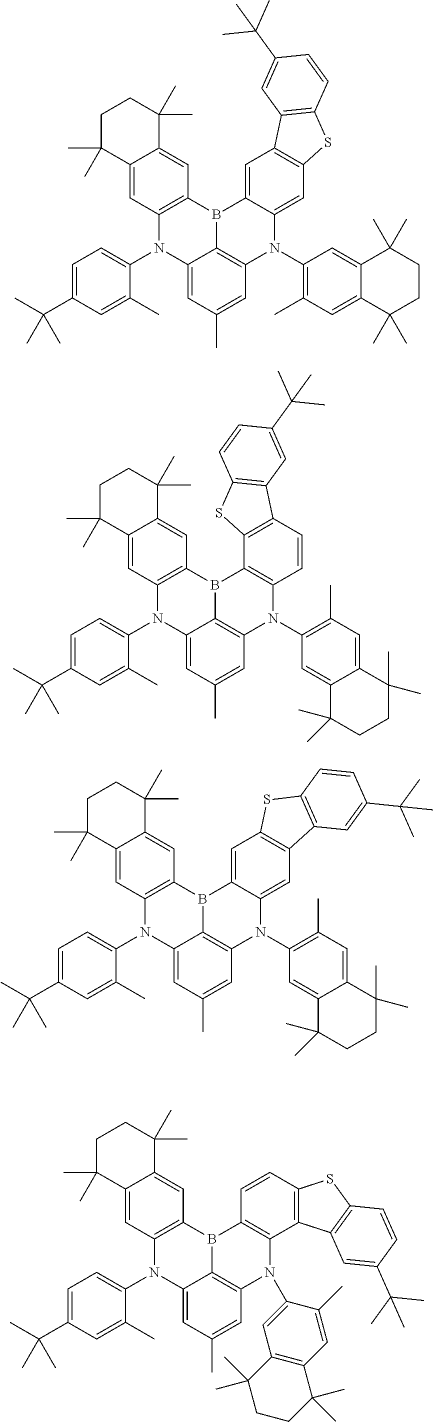

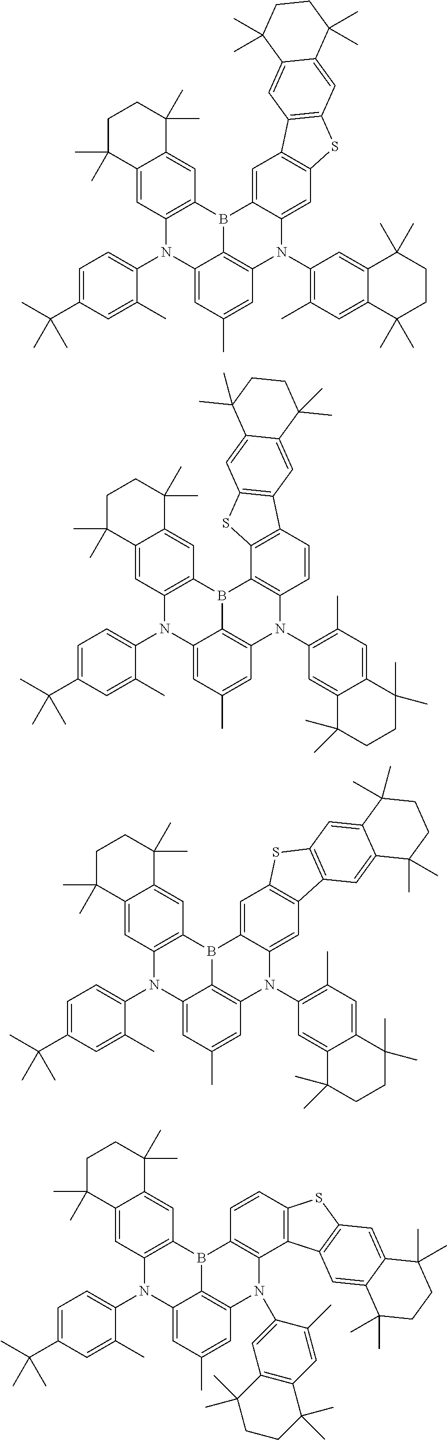

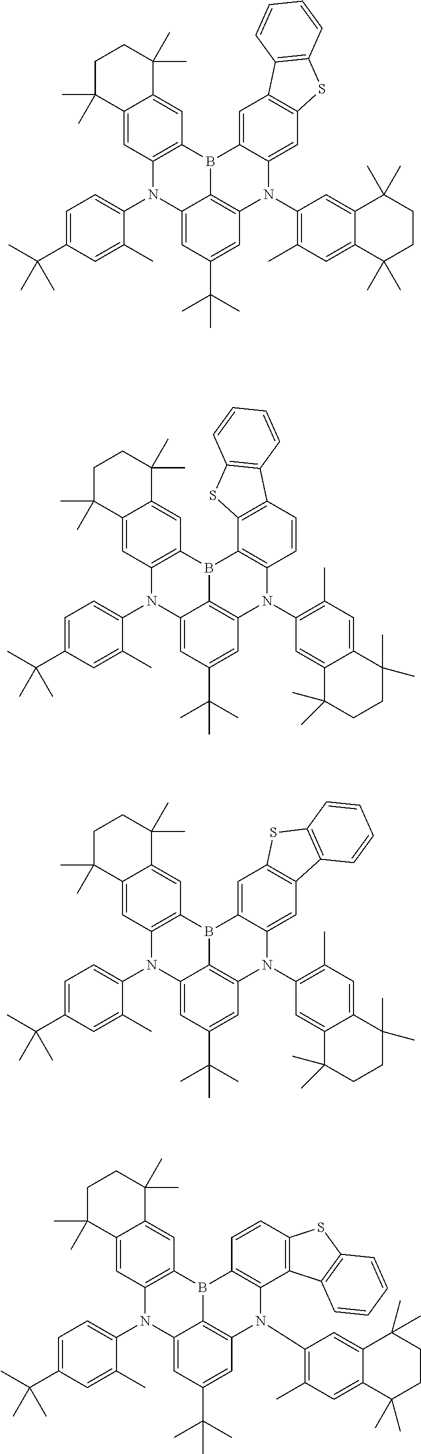

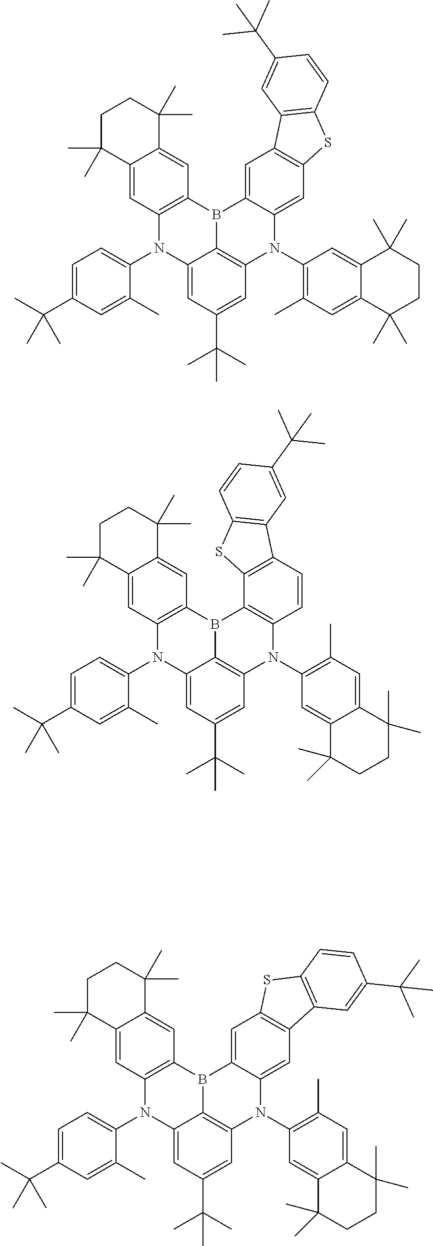

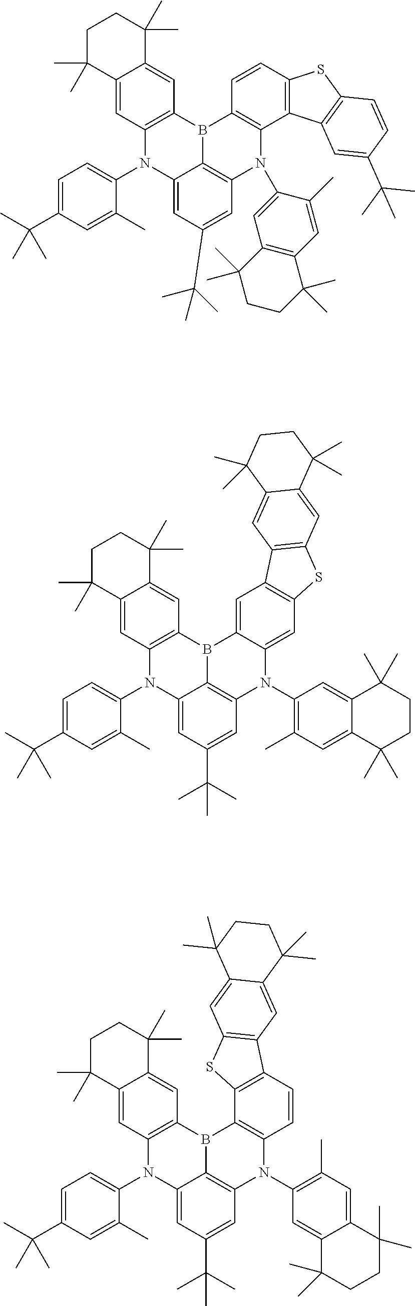

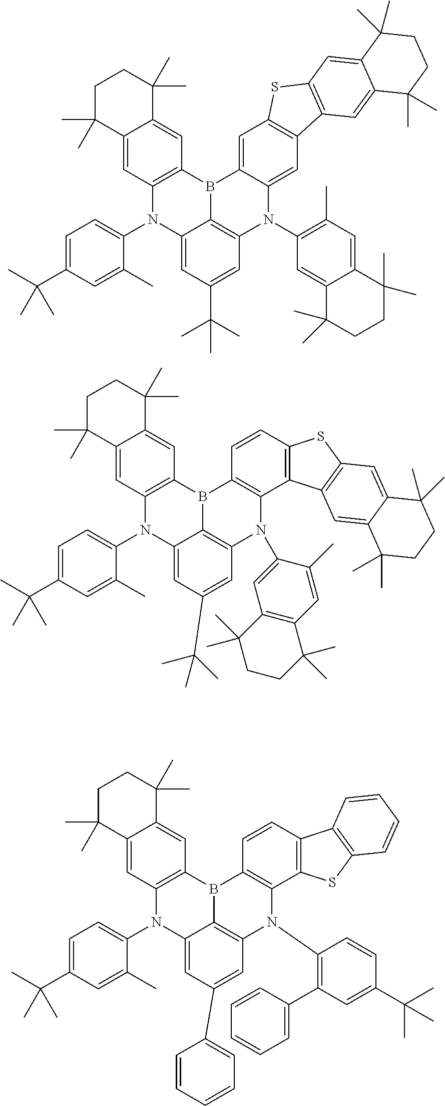

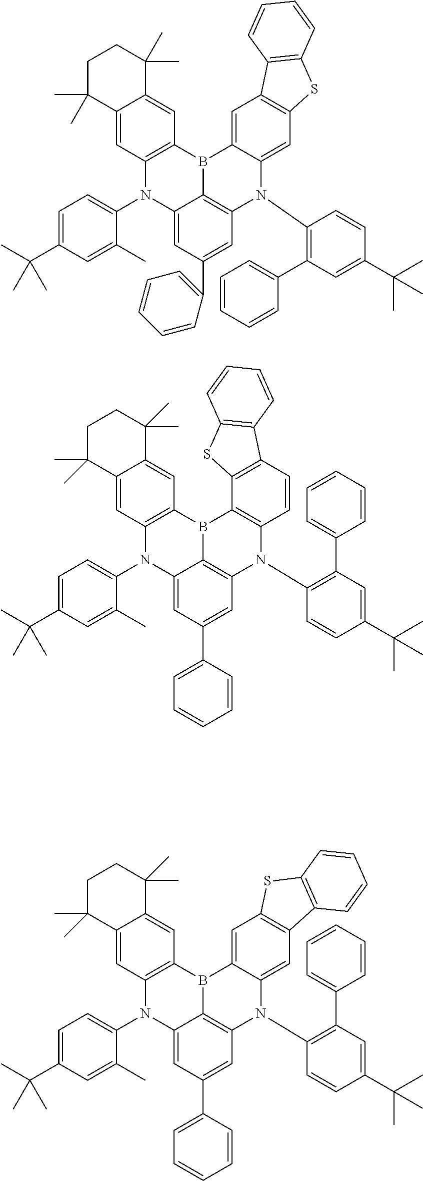

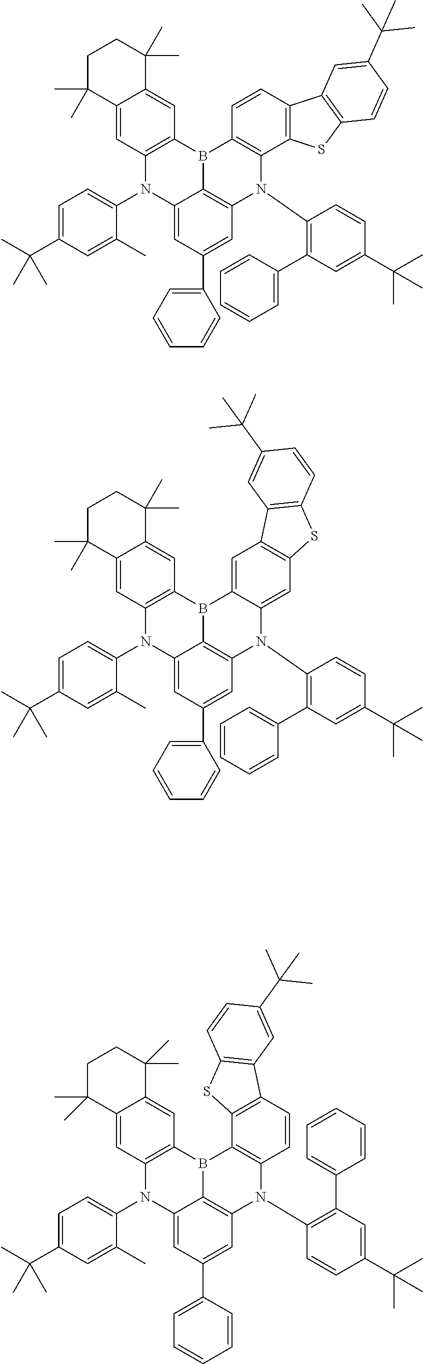

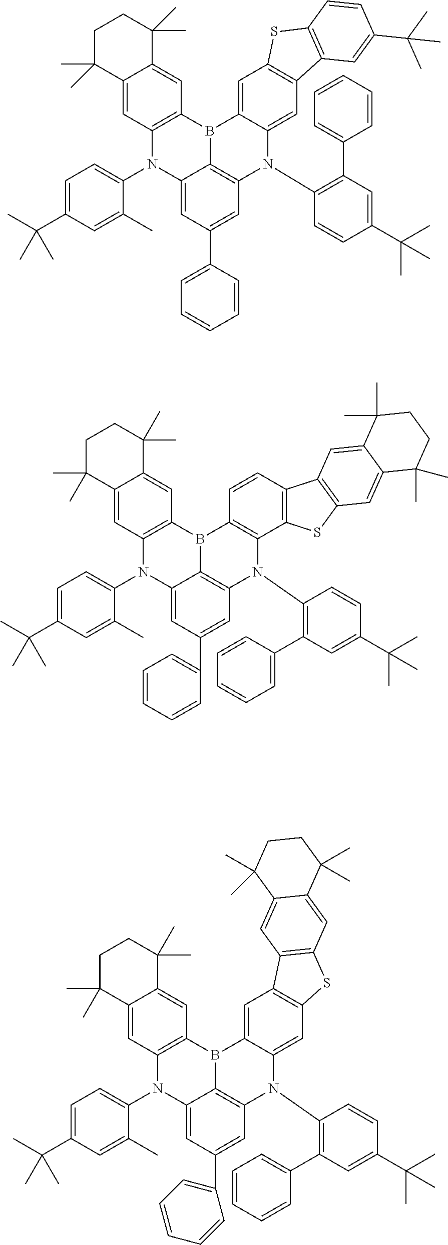

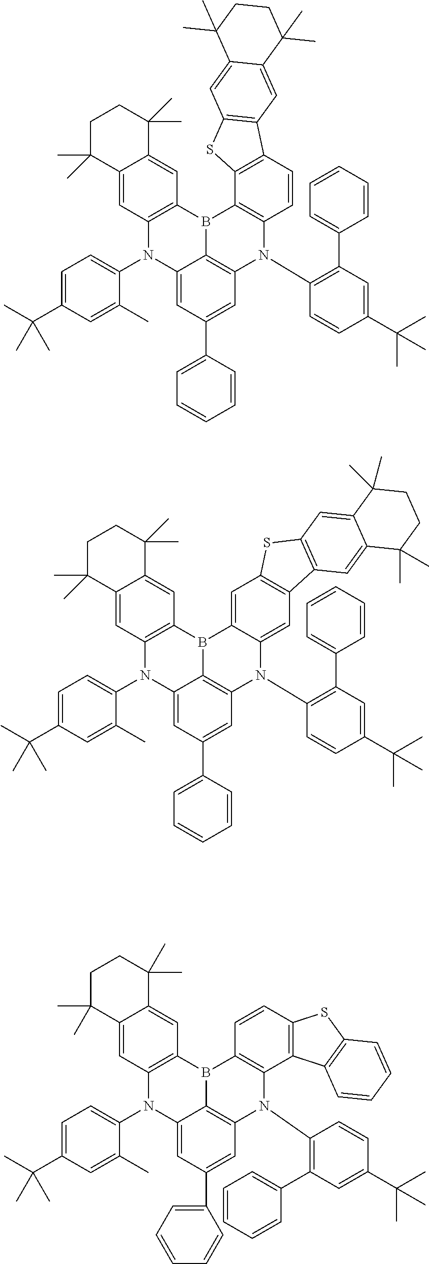

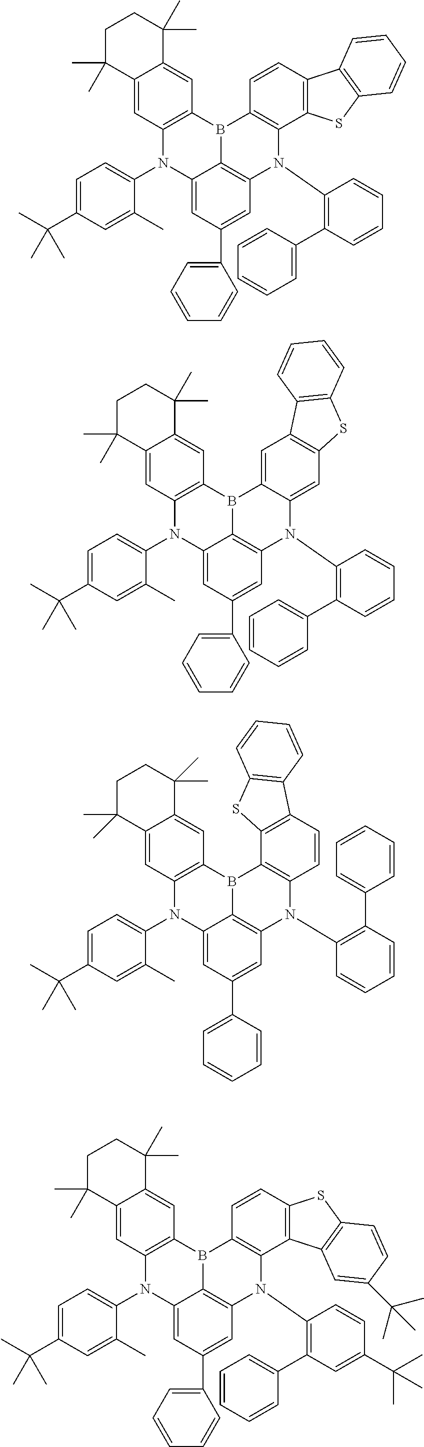

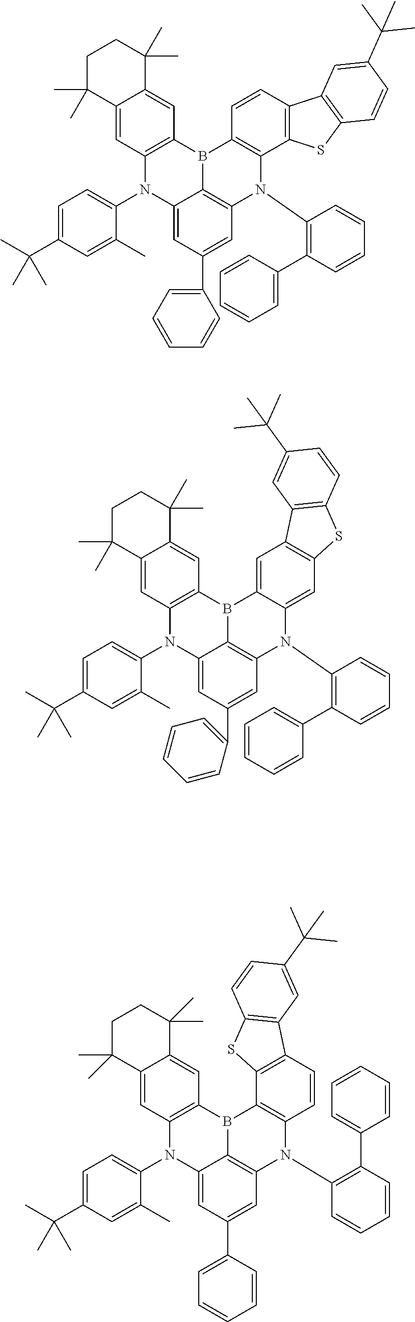

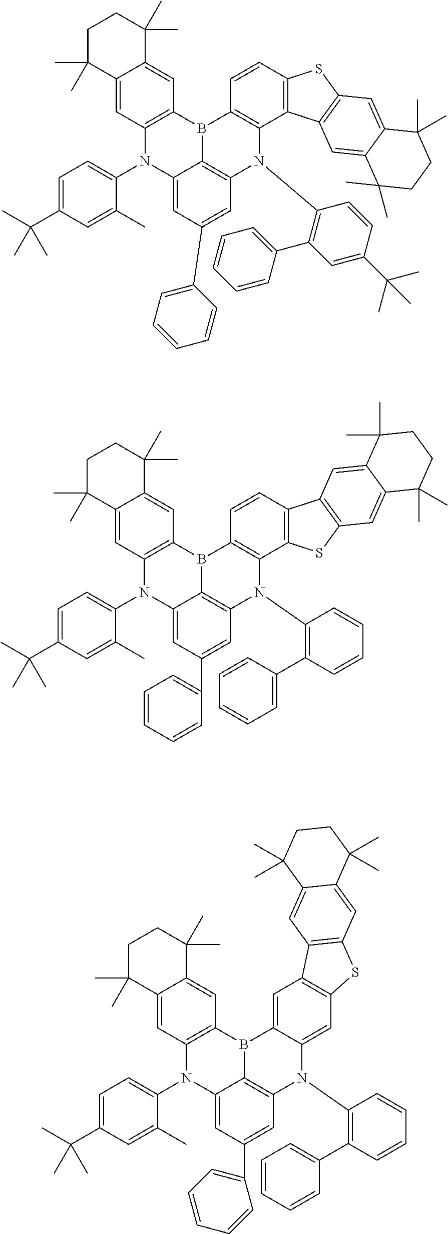

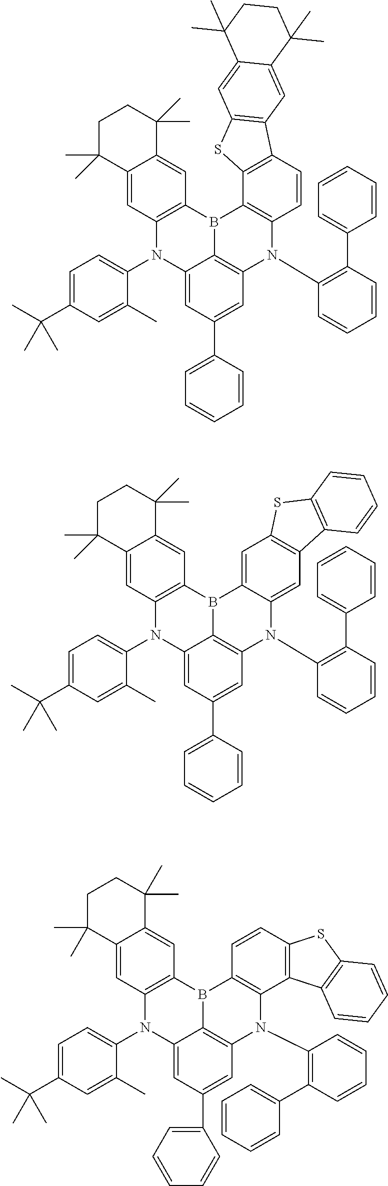 [SMILES: Cc1cc(C(C)(C)C)ccc1N1c2cc3c(cc2B2c4c1cc(-c1ccccc1)cc4N(c1ccccc1-c1ccccc1)c1ccc4c(sc5cc6c(cc54)C(C)(C)CCC6(C)C)c12)C(C)(C)CCC3(C)C ; Cc1cc(C(C)(C)C)ccc1N1c2cc3c(cc2B2c4cc5sc6ccccc6c5cc4N(c4ccccc4-c4ccccc4)c4cc(-c5ccccc5)cc1c42)C(C)(C)CCC3(C)C ; Cc1cc(C(C)(C)C)ccc1N1c2cc3c(cc2B2c4ccc5sc6ccccc6c5c4N(c4ccccc4-c4ccccc4)c4cc(-c5ccccc5)cc1c42)C(C)(C)CCC3(C)C]

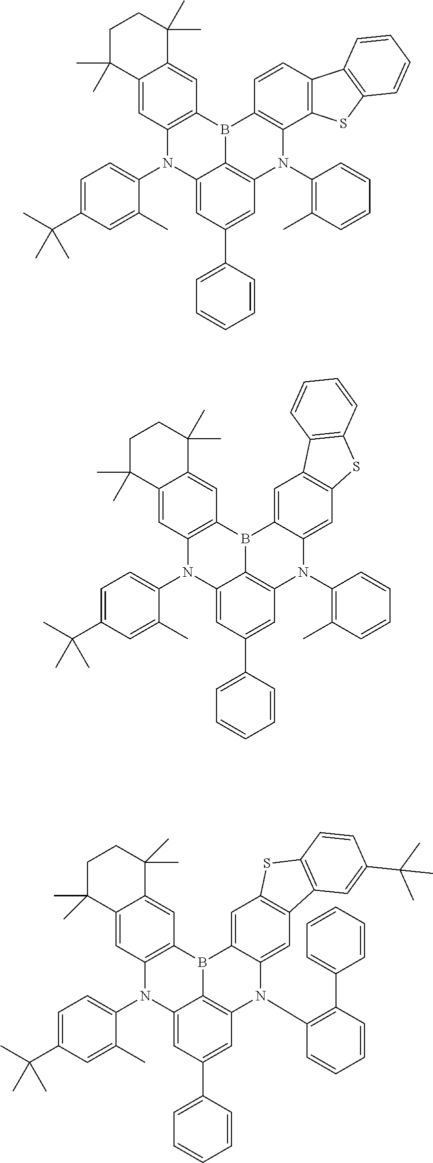 [SMILES: Cc1cc(C(C)(C)C)ccc1N1c2cc3c(cc2B2c4ccc5c(sc6ccccc65)c4N(c4ccccc4C)c4cc(-c5ccccc5)cc1c42)C(C)(C)CCC3(C)C ; Cc1cc(C(C)(C)C)ccc1N1c2cc3c(cc2B2c4cc5c(cc4N(c4ccccc4C)c4cc(-c6ccccc6)cc1c42)sc1ccccc15)C(C)(C)CCC3(C)C ; Cc1cc(C(C)(C)C)ccc1N1c2cc3c(cc2B2c4cc5sc6ccc(C(C)(C)C)cc6c5cc4N(c4ccccc4-c4ccccc4)c4cc(-c5ccccc5)cc1c42)C(C)(C)CCC3(C)C]

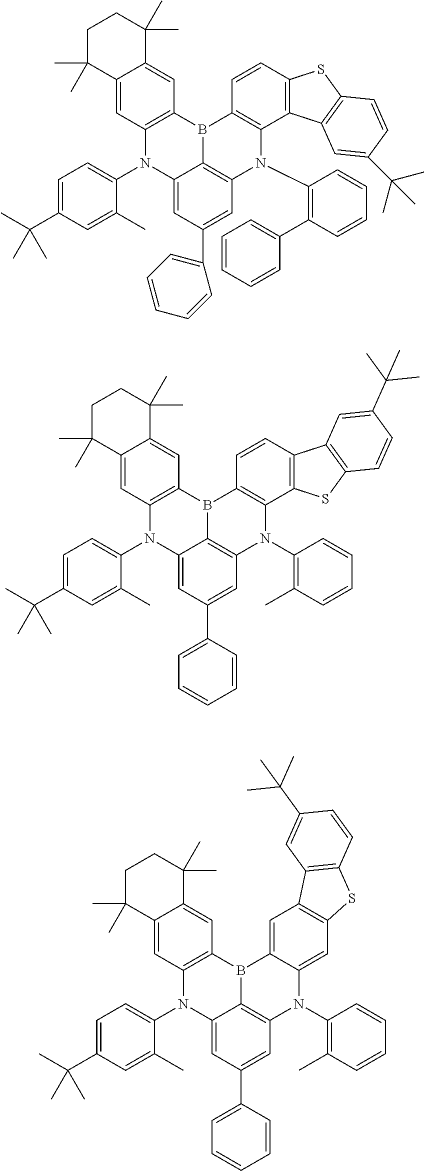

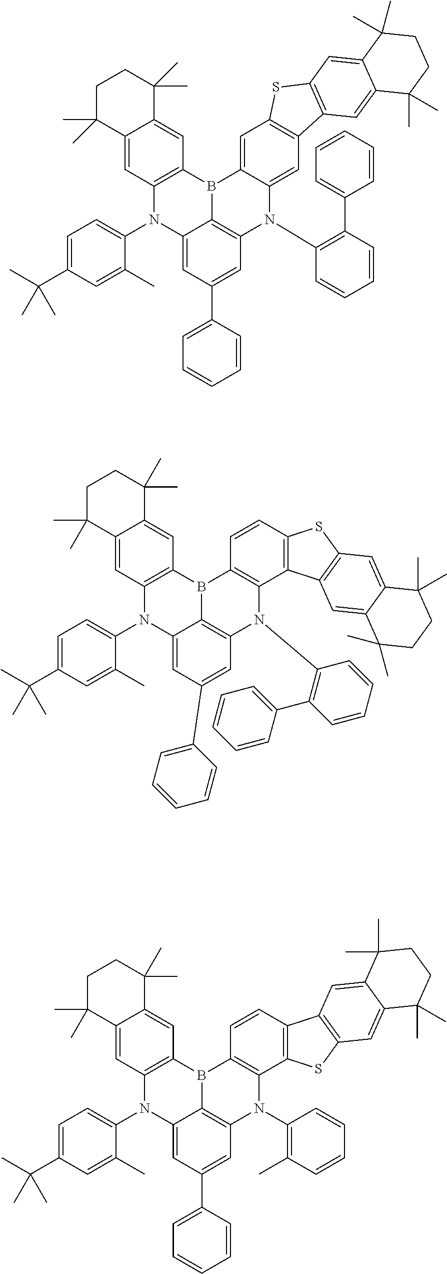

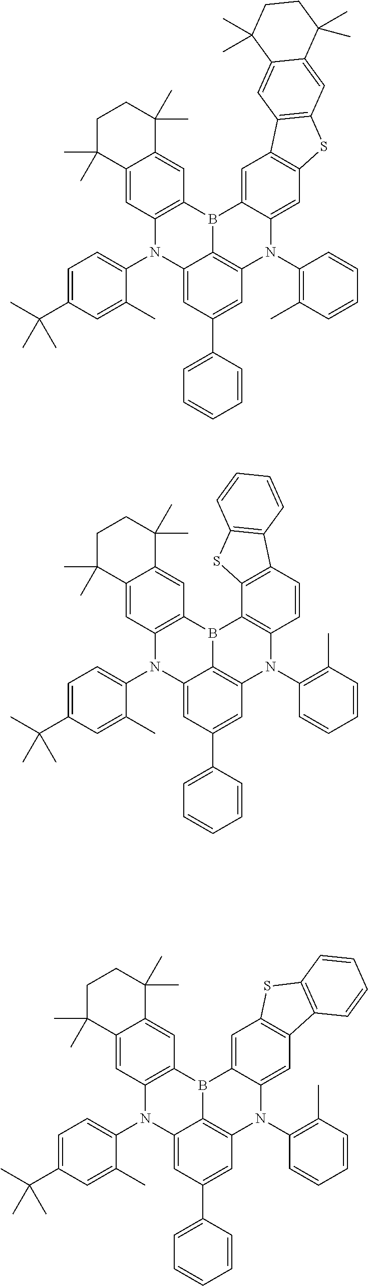 [SMILES: Cc1cc(C(C)(C)C)ccc1N1c2cc3c(cc2B2c4cc5c(cc4N(c4ccccc4C)c4cc(-c6ccccc6)cc1c42)sc1cc2c(cc15)C(C)(C)CCC2(C)C)C(C)(C)CCC3(C)C ; Cc1cc(C(C)(C)C)ccc1N1c2cc3c(cc2B2c4c1cc(-c1ccccc1)cc4N(c1ccccc1C)c1ccc4c(sc5ccccc54)c12)C(C)(C)CCC3(C)C ; Cc1cc(C(C)(C)C)ccc1N1c2cc3c(cc2B2c4cc5sc6ccccc6c5cc4N(c4ccccc4C)c4cc(-c5ccccc5)cc1c42)C(C)(C)CCC3(C)C]

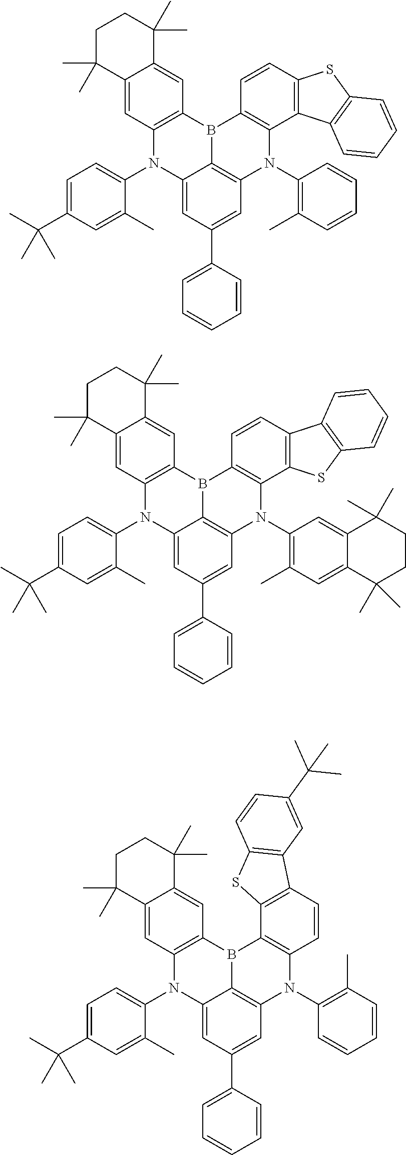

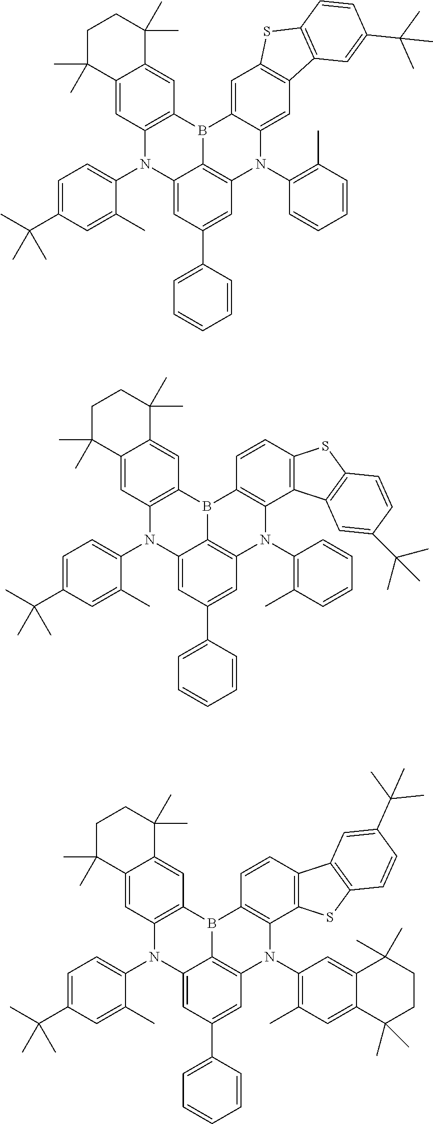

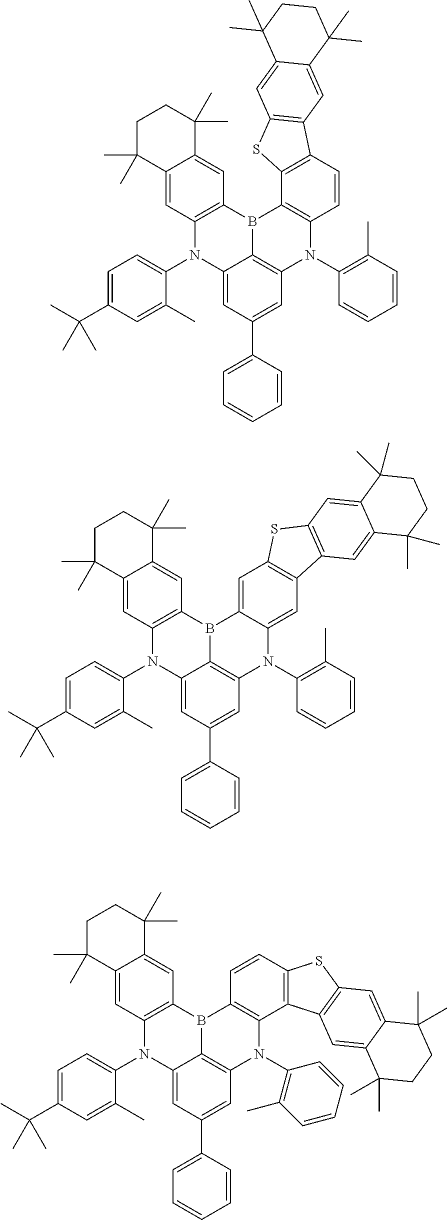

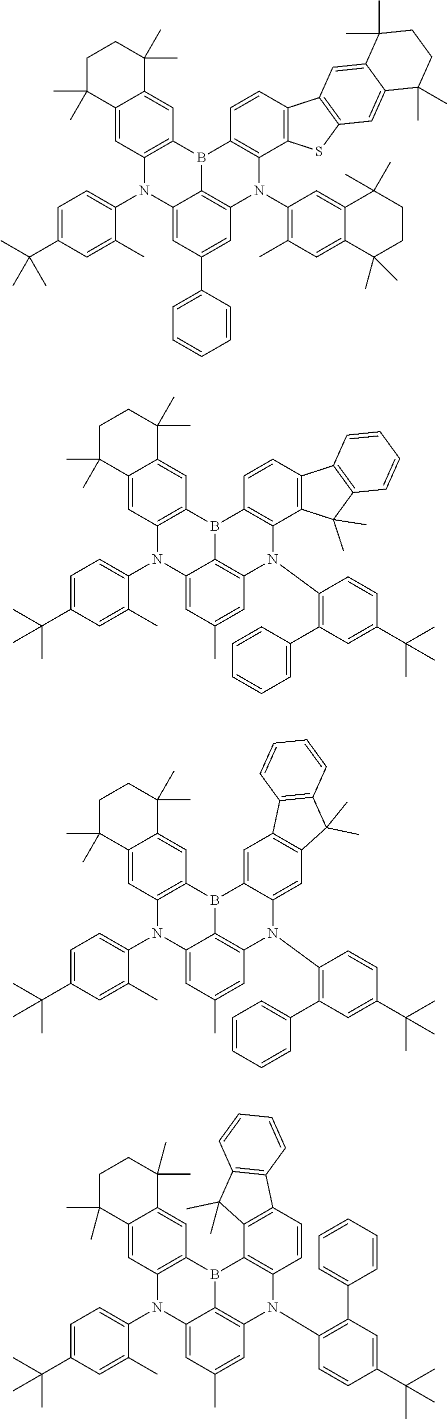

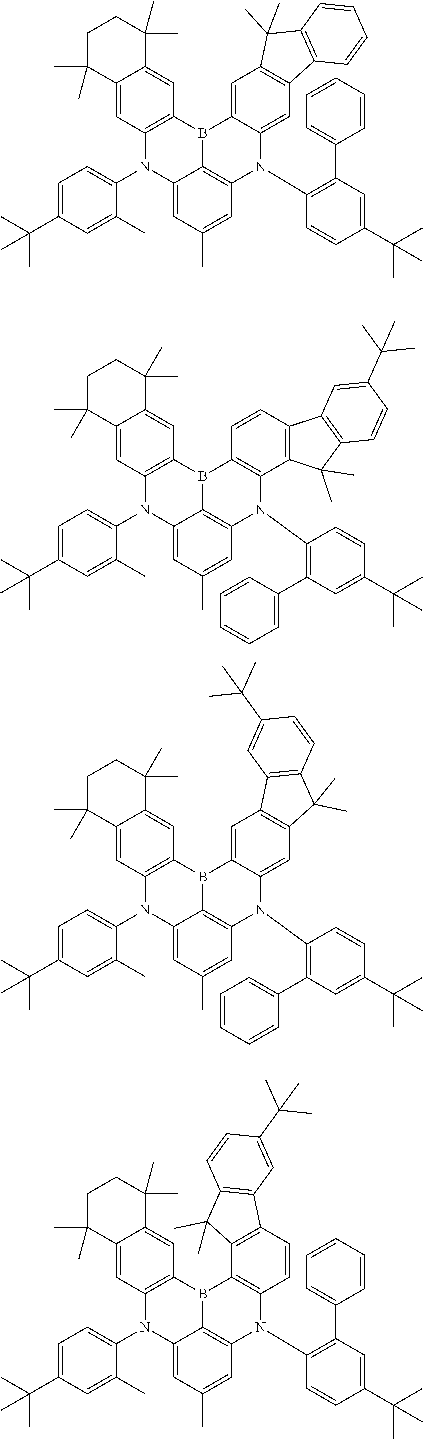

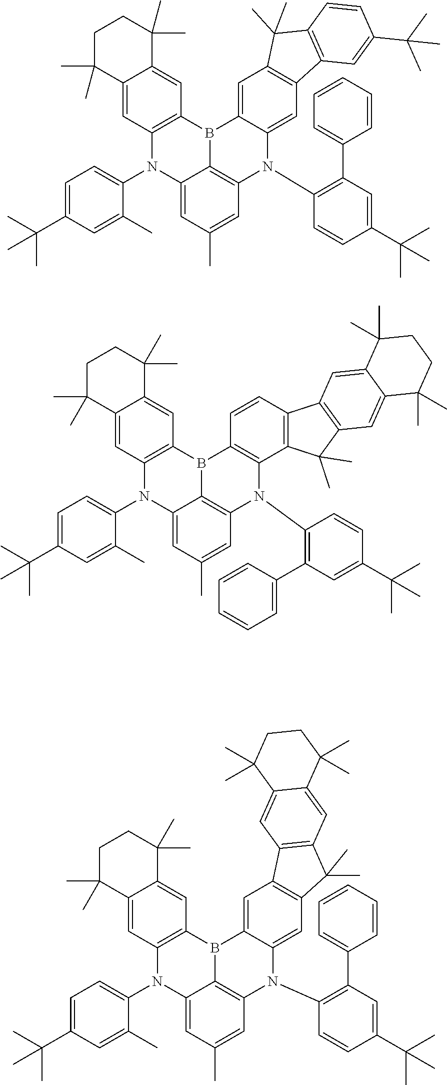

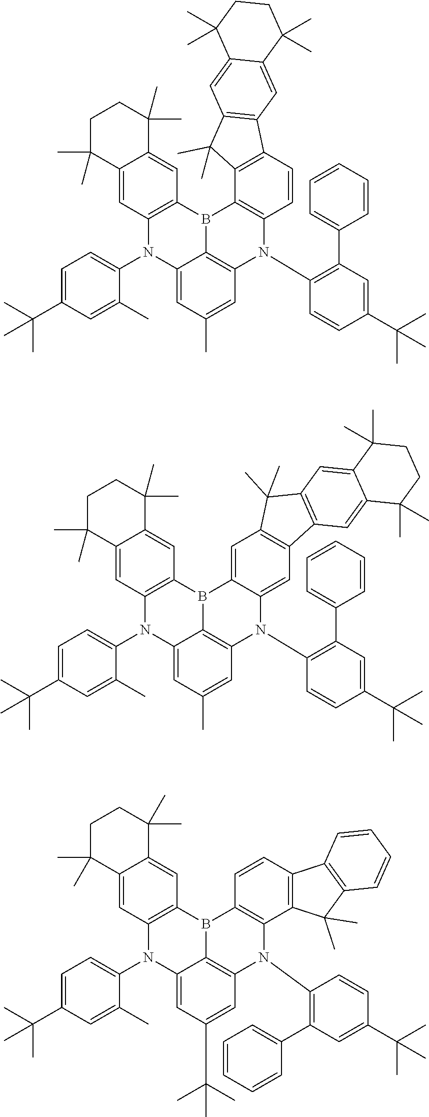

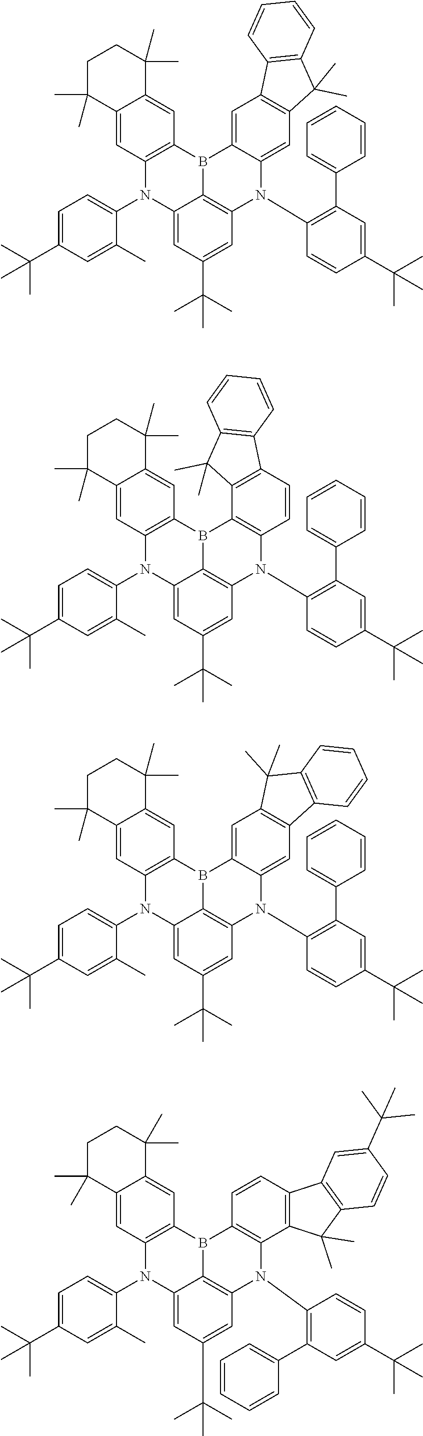

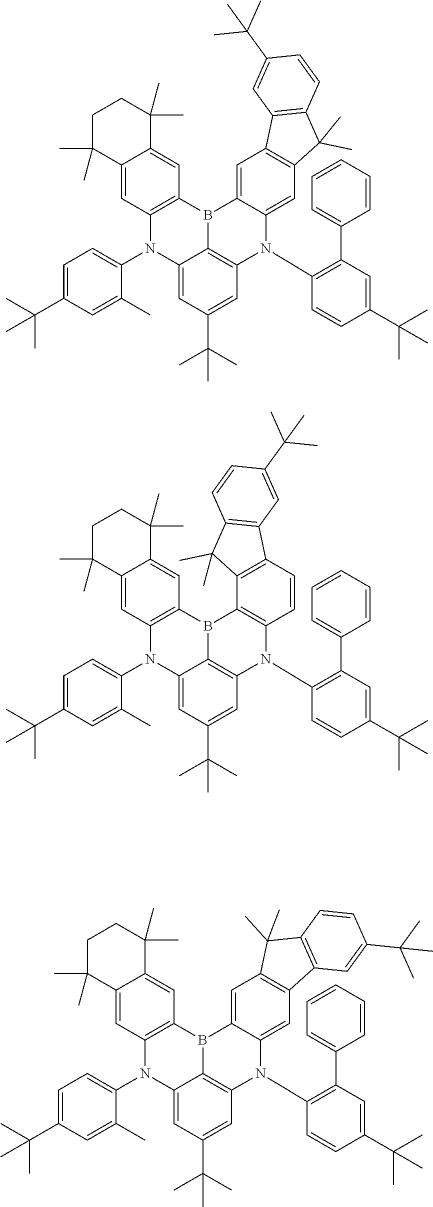

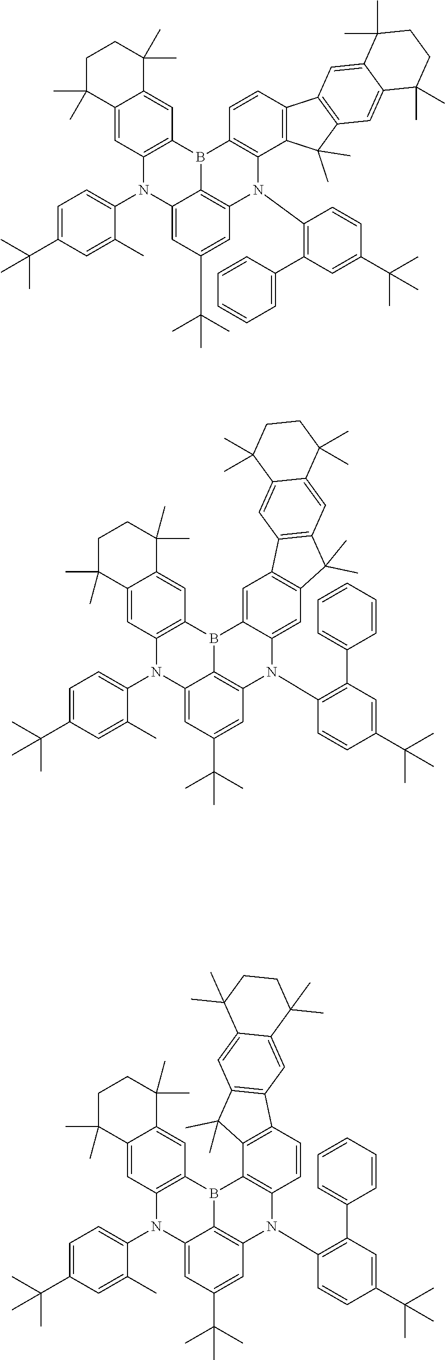

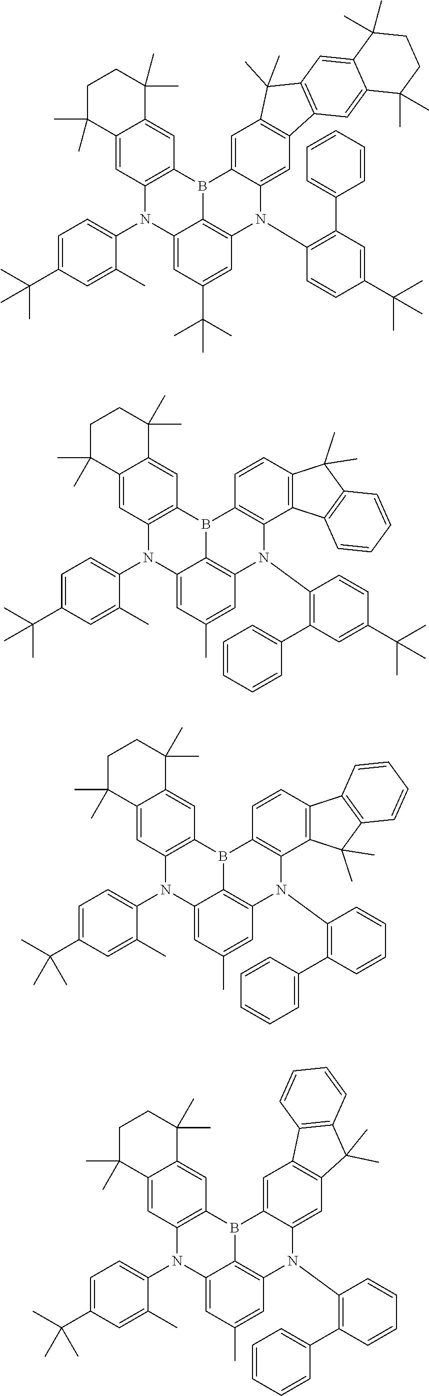

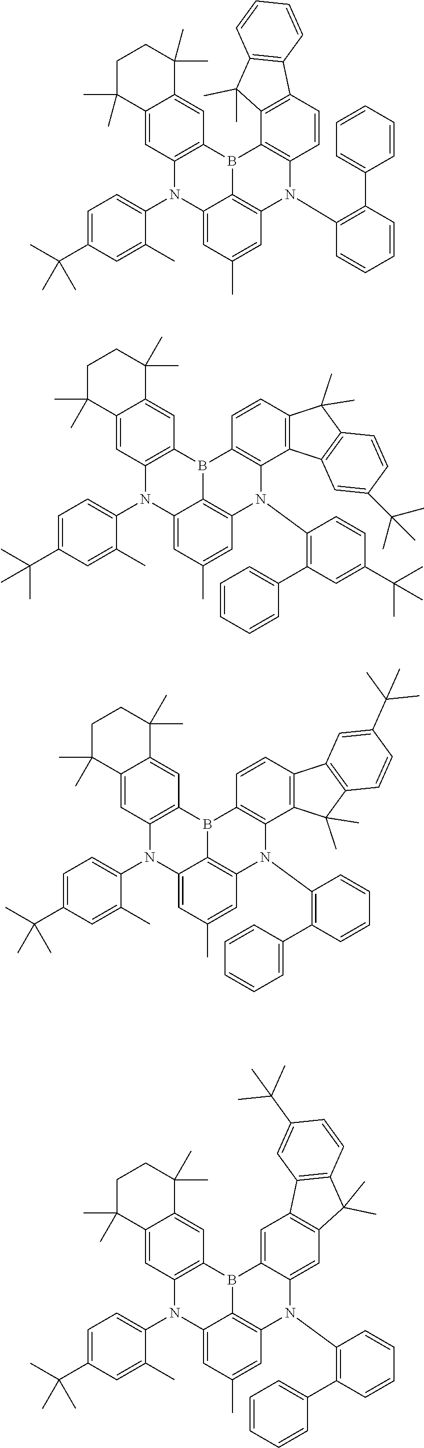

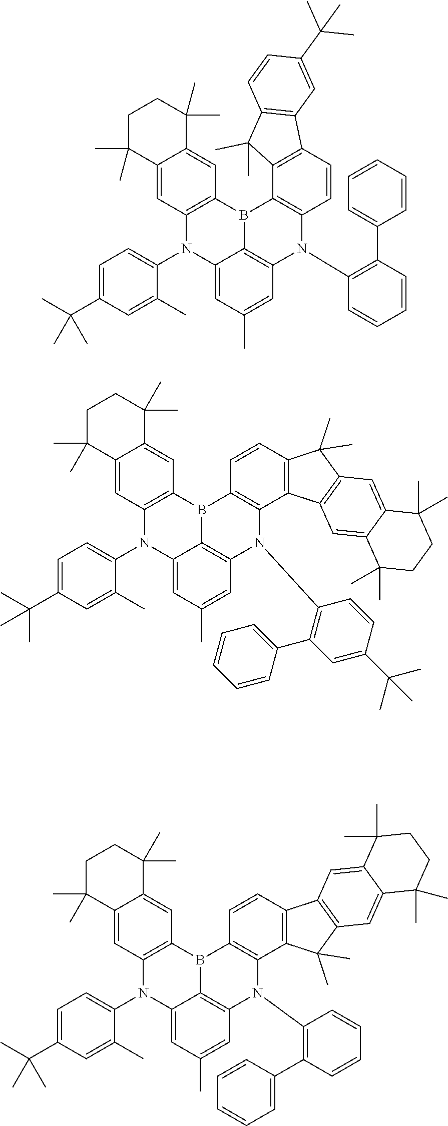

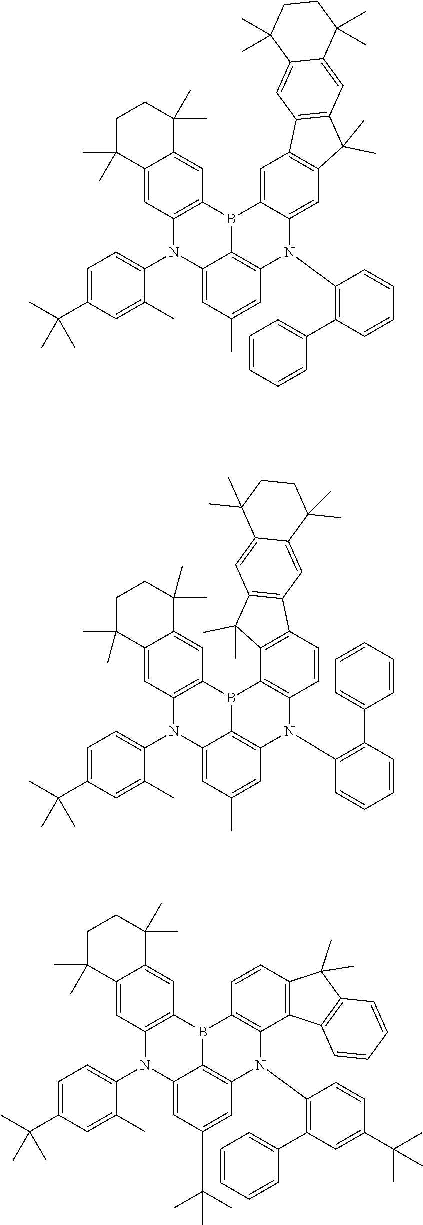 [SMILES: Cc1cc2c3c(c1)N(c1ccccc1-c1ccccc1)c1cc4c(cc1B3c1cc3c(cc1N2c1ccc(C(C)(C)C)cc1C)C(C)(C)CCC3(C)C)-c1cc2c(cc1C4(C)C)C(C)(C)CCC2(C)C ; Cc1cc2c3c(c1)N(c1ccccc1-c1ccccc1)c1ccc4c(c1B3c1cc3c(cc1N2c1ccc(C(C)(C)C)cc1C)C(C)(C)CCC3(C)C)C(C)(C)c1cc2c(cc1-4)C(C)(C)CCC2(C)C ; Cc1cc(C(C)(C)C)ccc1N1c2cc3c(cc2B2c4ccc5c(c4N(c4ccc(C(C)(C)C)cc4-c4ccccc4)c4cc(C(C)(C)C)cc1c42)-c1ccccc1C5(C)C)C(C)(C)CCC3(C)C]

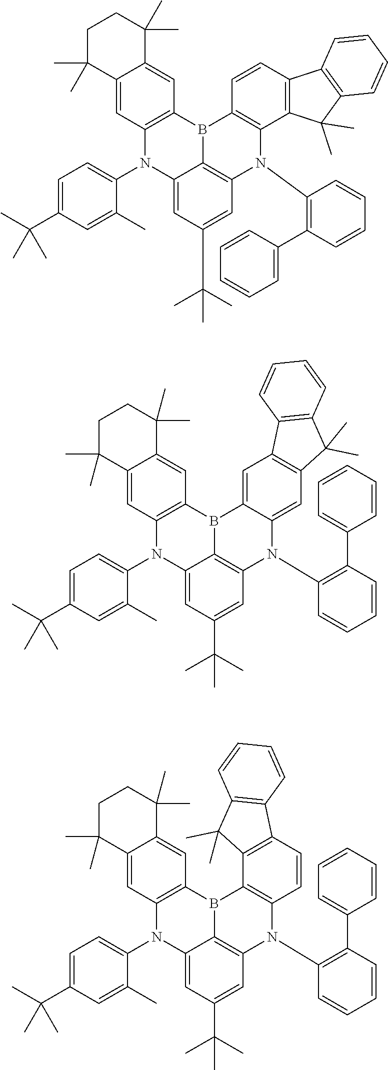 [SMILES: Cc1cc(C(C)(C)C)ccc1N1c2cc3c(cc2B2c4ccc5c(c4N(c4ccccc4-c4ccccc4)c4cc(C(C)(C)C)cc1c42)C(C)(C)c1ccccc1-5)C(C)(C)CCC3(C)C ; Cc1cc(C(C)(C)C)ccc1N1c2cc3c(cc2B2c4cc5c(cc4N(c4ccccc4-c4ccccc4)c4cc(C(C)(C)C)cc1c42)C(C)(C)c1ccccc1-5)C(C)(C)CCC3(C)C ; Cc1cc(C(C)(C)C)ccc1N1c2cc3c(cc2B2c4c1cc(C(C)(C)C)cc4N(c1ccccc1-c1ccccc1)c1ccc4c(c12)C(C)(C)c1ccccc1-4)C(C)(C)CCC3(C)C]

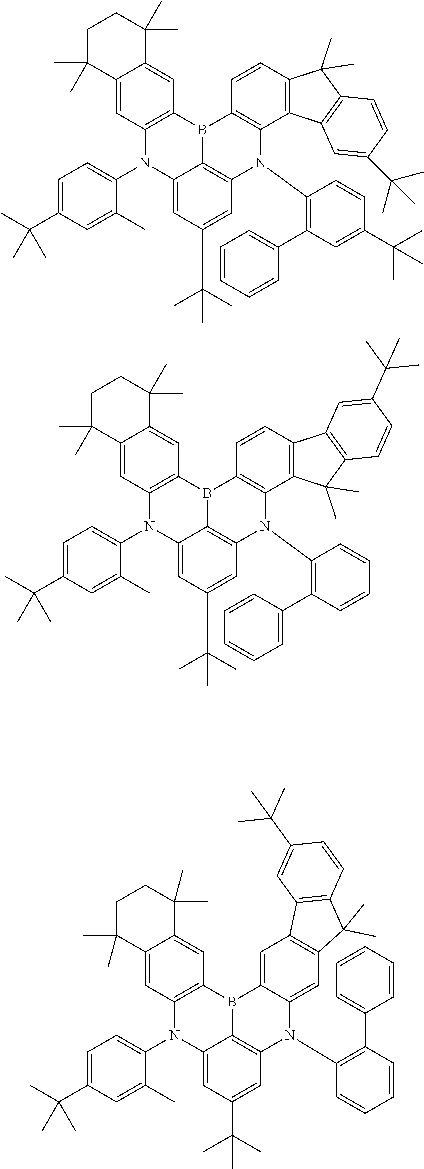

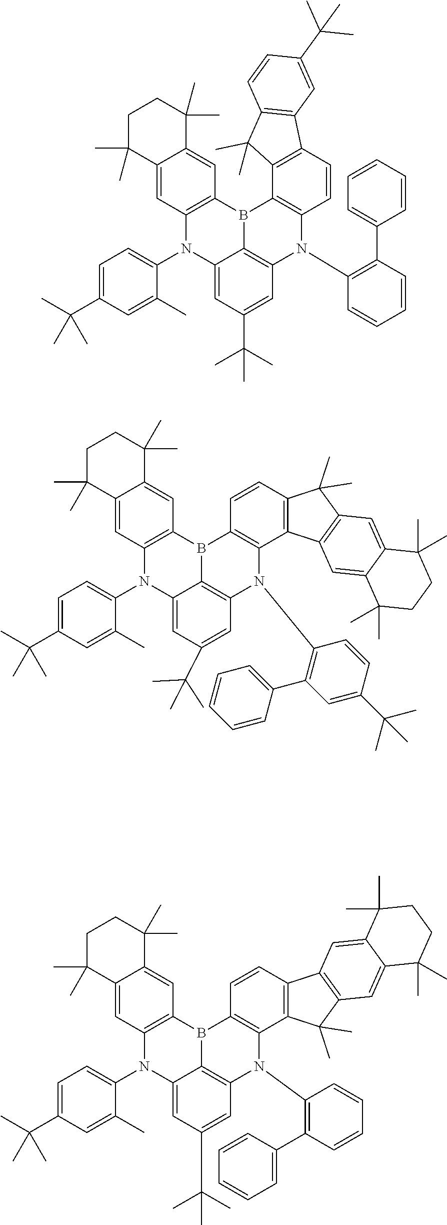

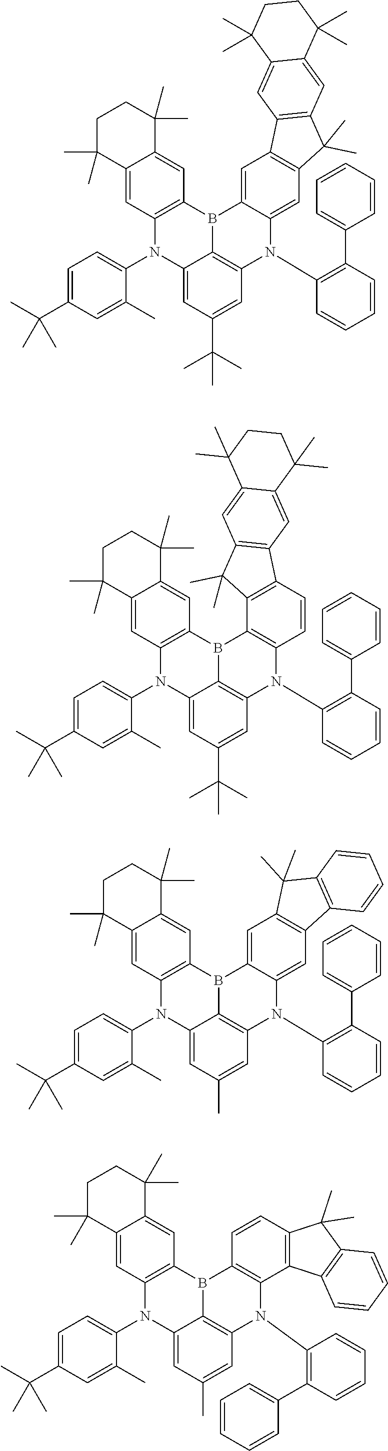

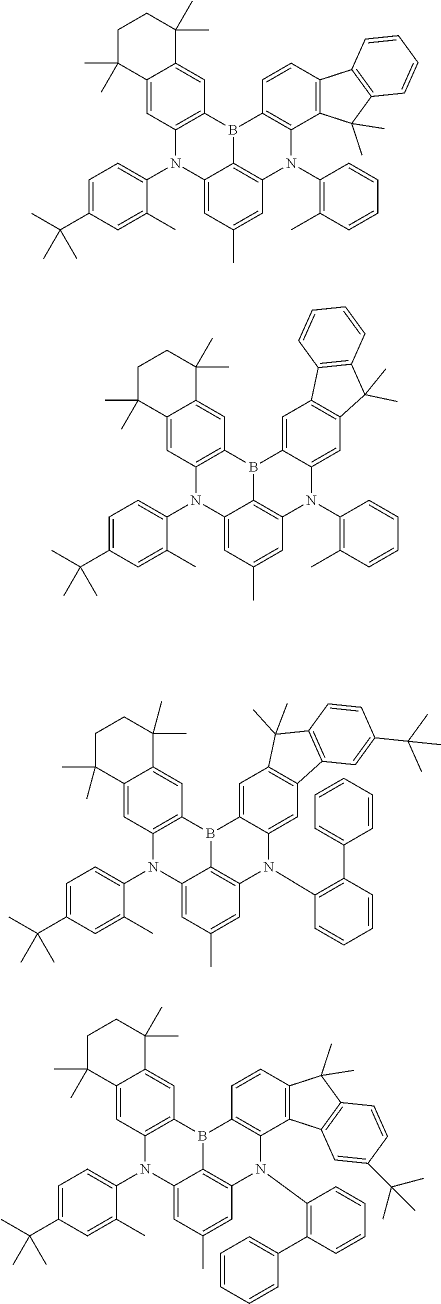

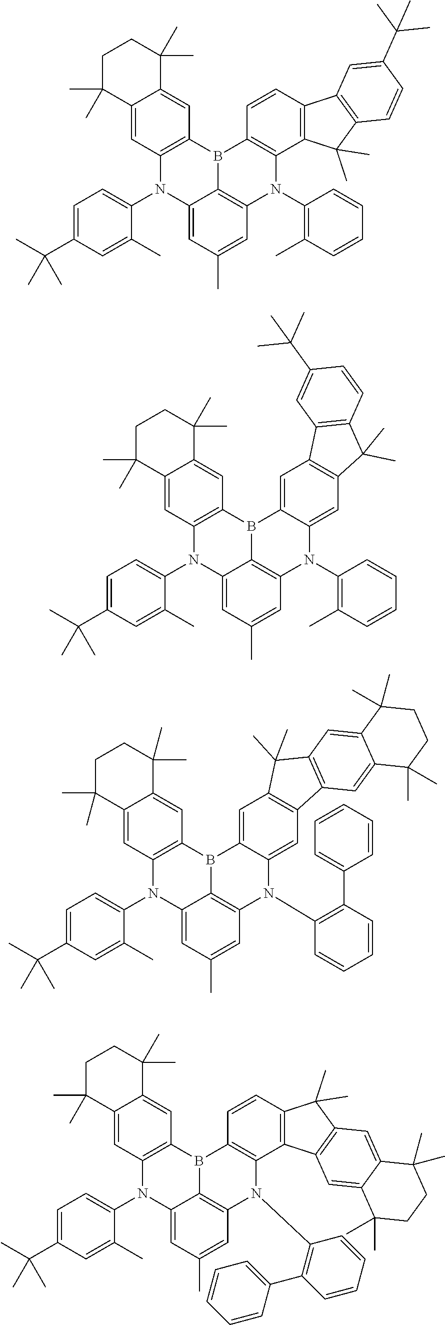

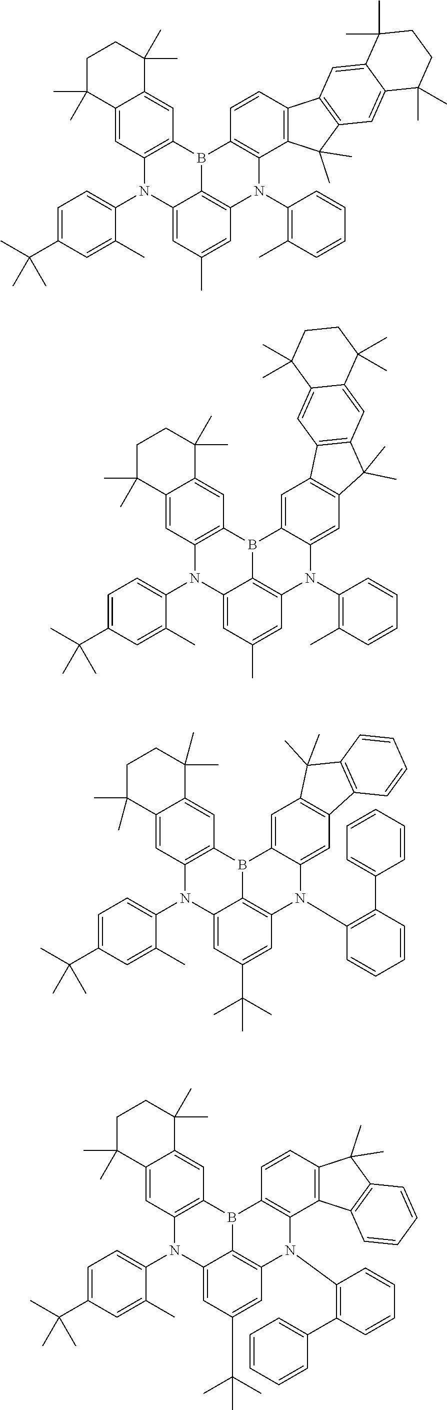

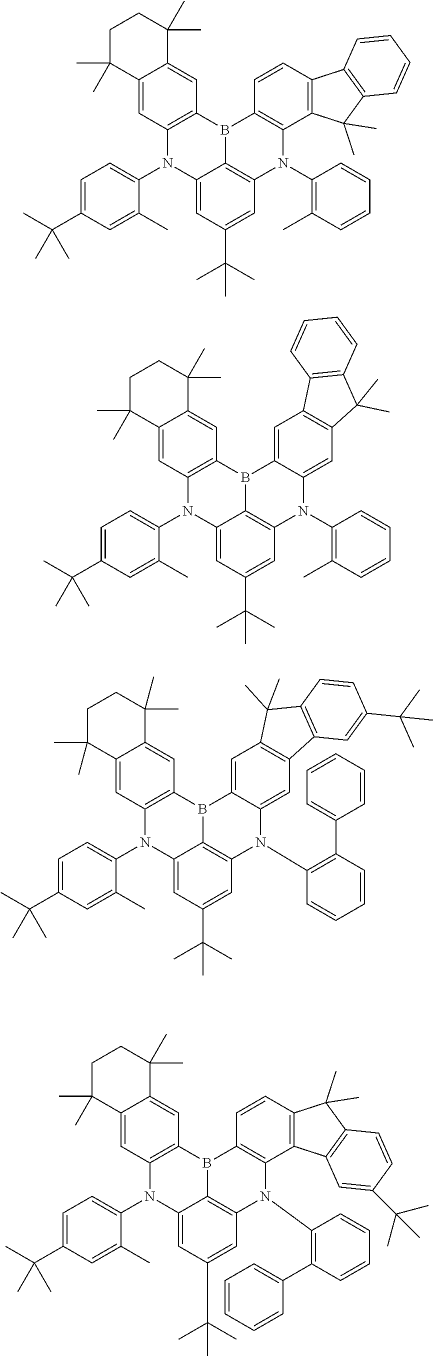

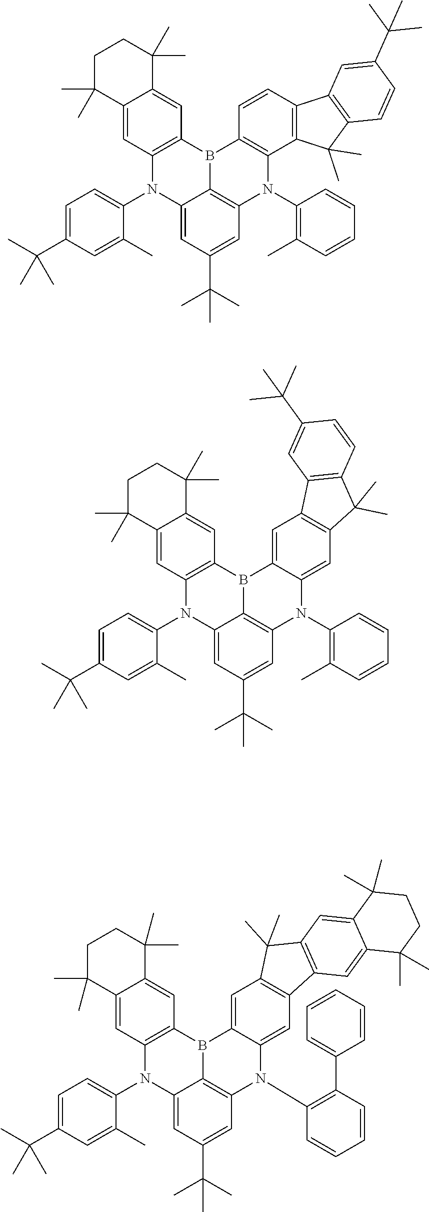

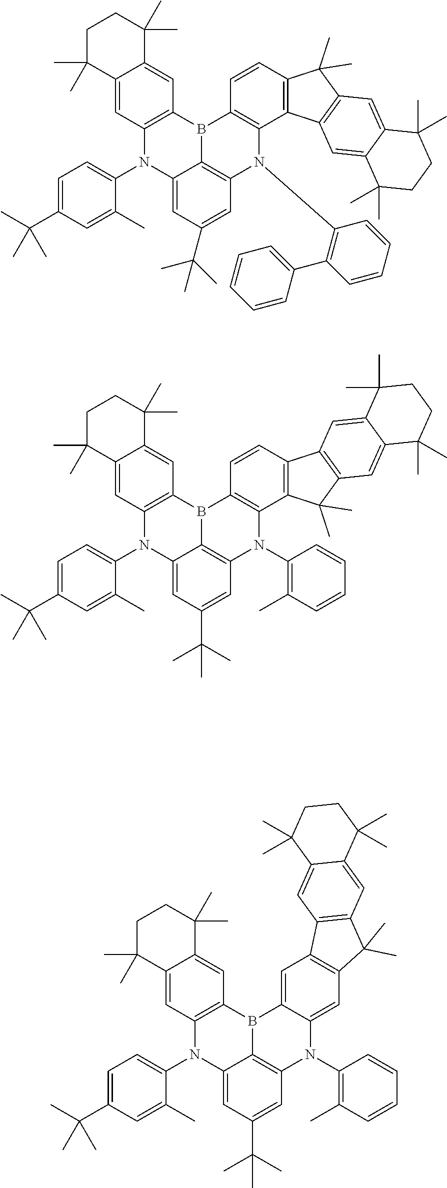

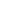

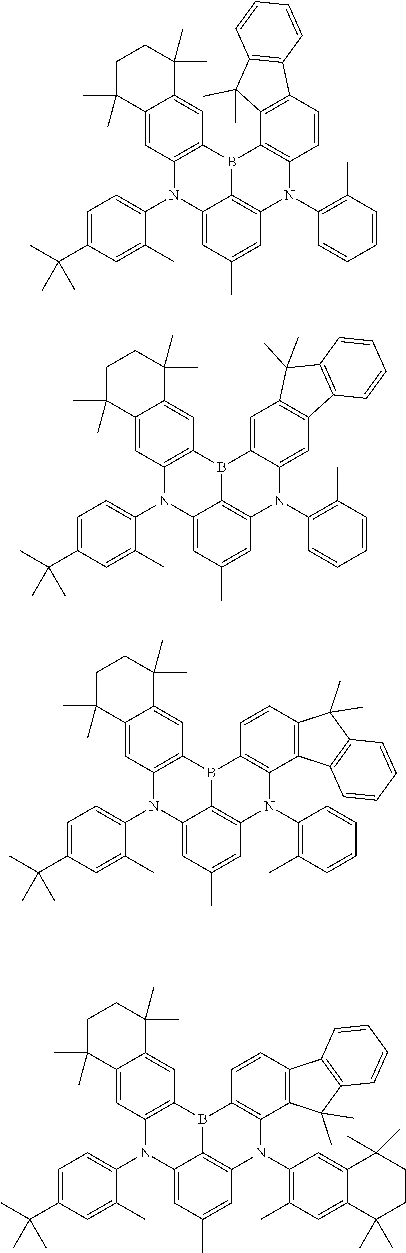 [SMILES: Cc1cc2c3c(c1)N(c1ccccc1C)c1ccc4c(c1B3c1cc3c(cc1N2c1ccc(C(C)(C)C)cc1C)C(C)(C)CCC3(C)C)C(C)(C)c1ccccc1-4 ; Cc1cc2c3c(c1)N(c1ccc(C(C)(C)C)cc1C)c1cc4c(cc1B3c1cc3c(cc1N2c1ccccc1C)-c1ccccc1C3(C)C)C(C)(C)CCC4(C)C ; Cc1cc2c3c(c1)N(c1ccccc1C)c1c(ccc4c1-c1ccccc1C4(C)C)B3c1cc3c(cc1N2c1ccc(C(C)(C)C)cc1C)C(C)(C)CCC3(C)C ; Cc1cc2c3c(c1)N(c1cc4c(cc1C)C(C)(C)CCC4(C)C)c1c(ccc4c1C(C)(C)c1ccccc1-4)B3c1cc3c(cc1N2c1ccc(C(C)(C)C)cc1C)C(C)(C)CCC3(C)C]

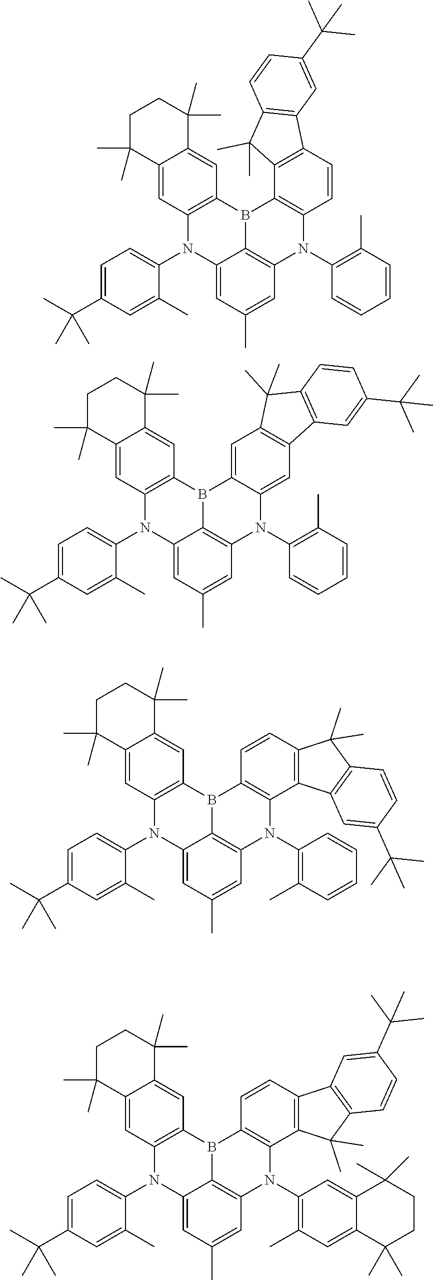

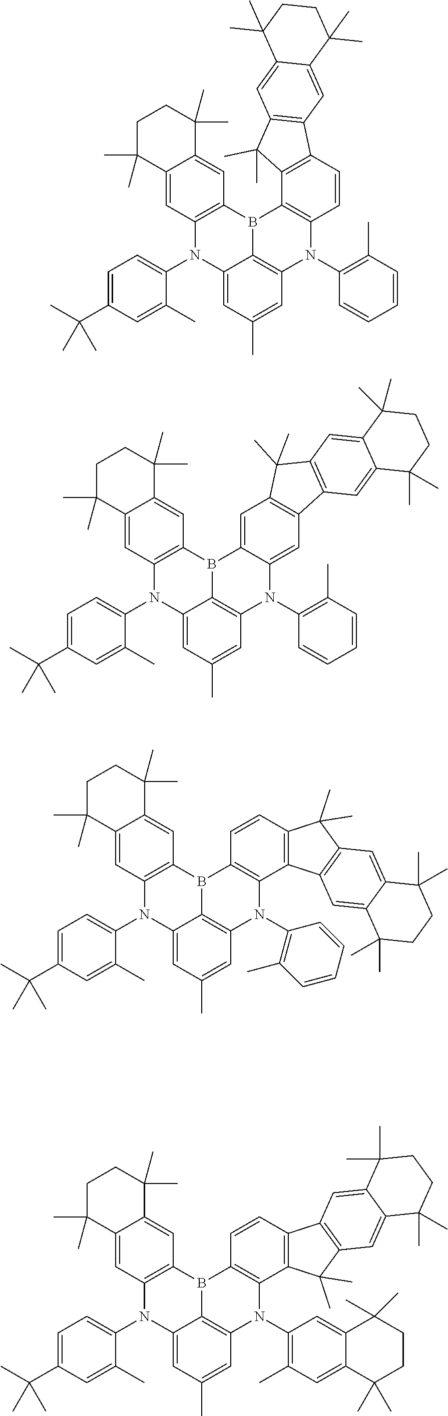

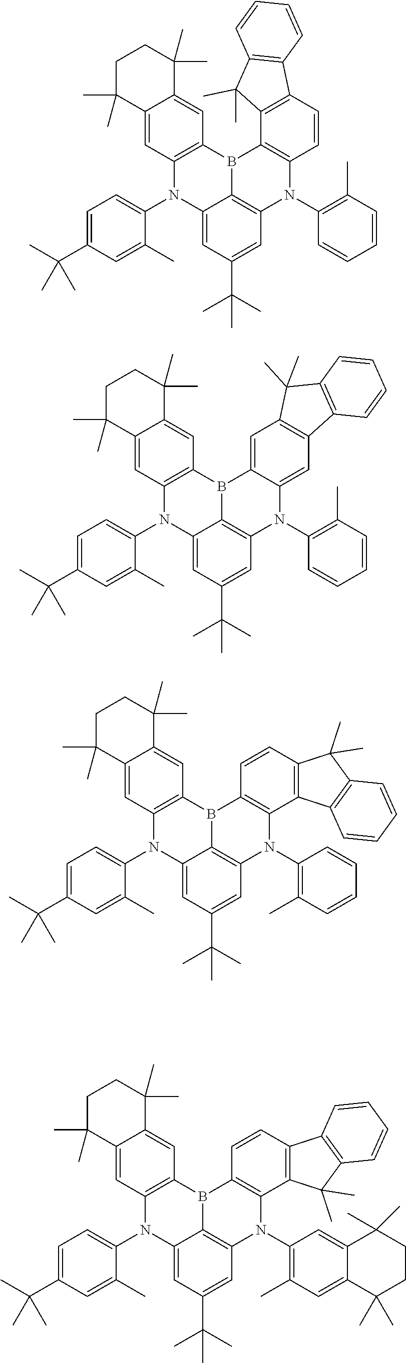 [SMILES: Cc1cc(C(C)(C)C)ccc1N1c2cc3c(cc2B2c4c1cc(C(C)(C)C)cc4N(c1ccccc1C)c1ccc4c(c12)C(C)(C)c1ccccc1-4)C(C)(C)CCC3(C)C ; Cc1ccccc1N1c2cc3c(cc2B2c4cc5c(cc4N(c4ccc(C(C)(C)C)cc4C)c4cc(C(C)(C)C)cc1c42)C(C)(C)CCC5(C)C)C(C)(C)c1ccccc1-3 ; Cc1cc(C(C)(C)C)ccc1N1c2cc3c(cc2B2c4ccc5c(c4N(c4ccccc4C)c4cc(C(C)(C)C)cc1c42)-c1ccccc1C5(C)C)C(C)(C)CCC3(C)C ; Cc1cc(C(C)(C)C)ccc1N1c2cc3c(cc2B2c4ccc5c(c4N(c4cc6c(cc4C)C(C)(C)CCC6(C)C)c4cc(C(C)(C)C)cc1c42)C(C)(C)c1ccccc1-5)C(C)(C)CCC3(C)C]

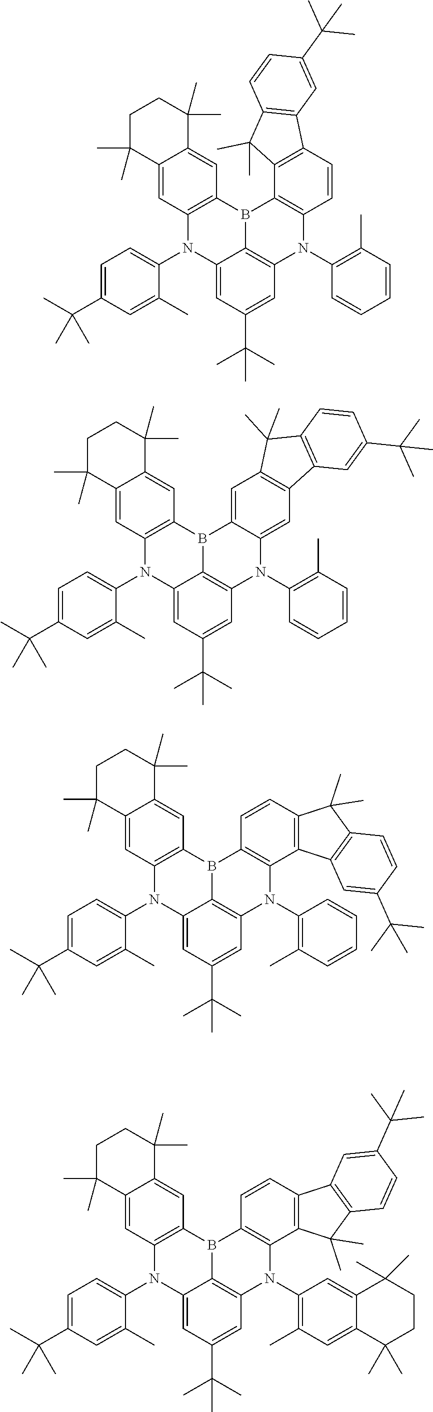

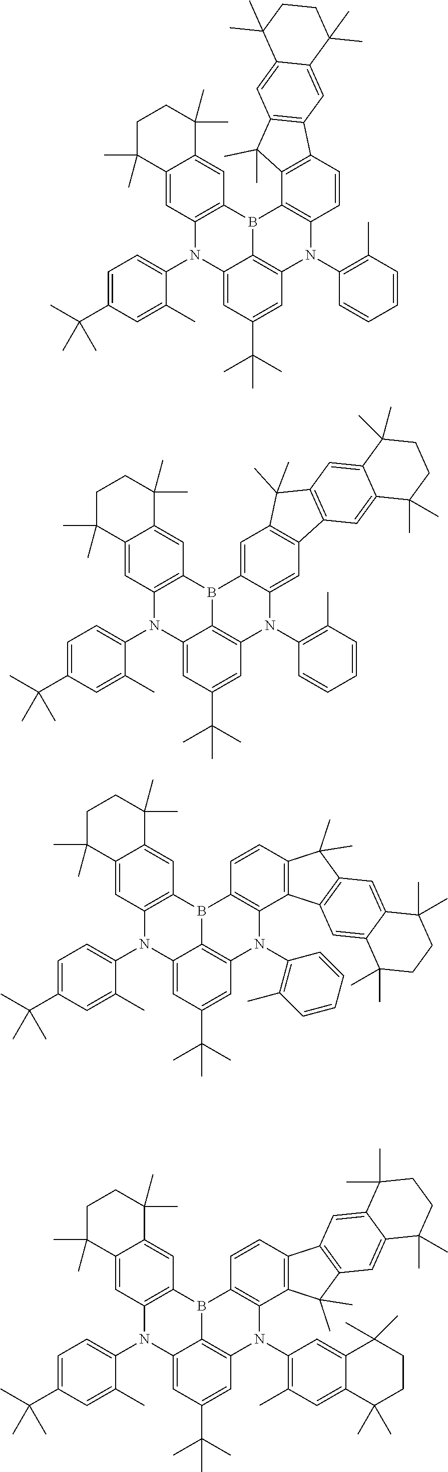

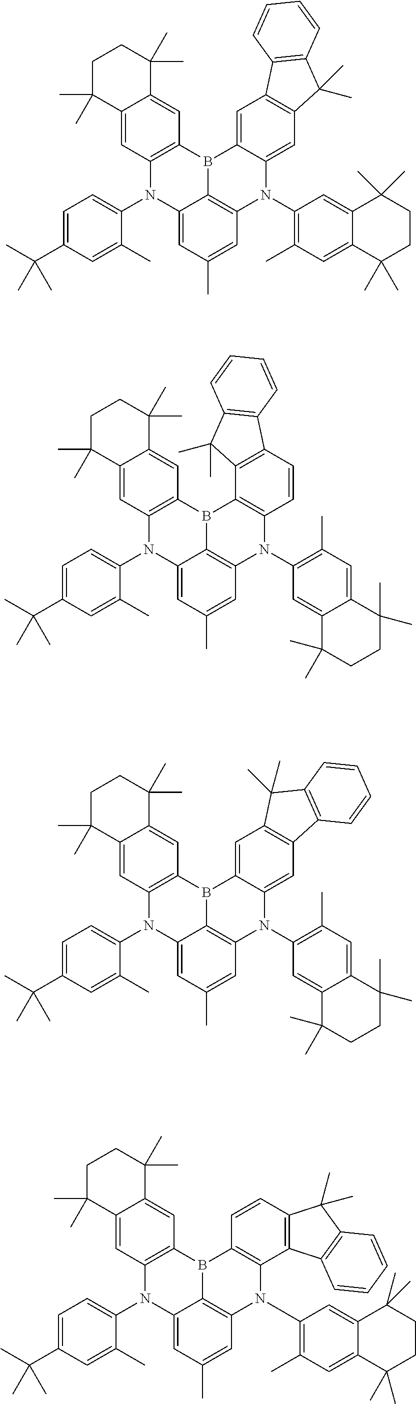

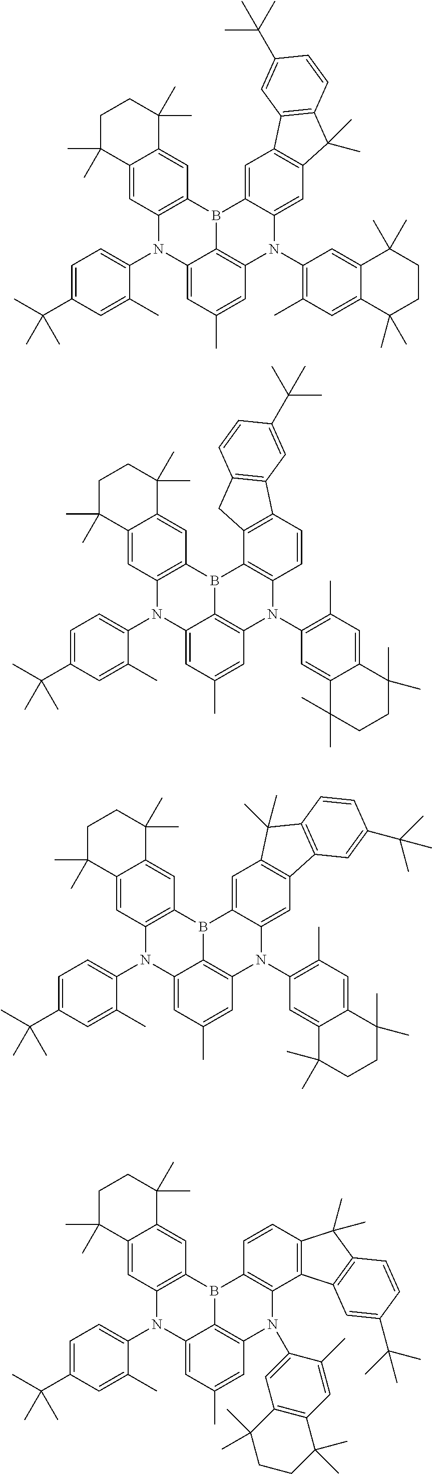

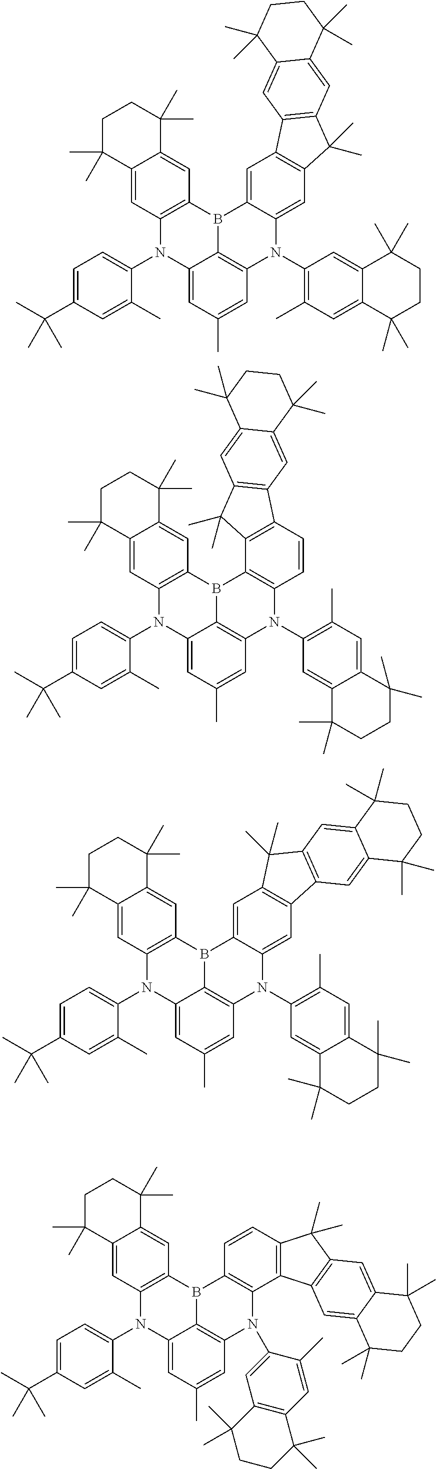

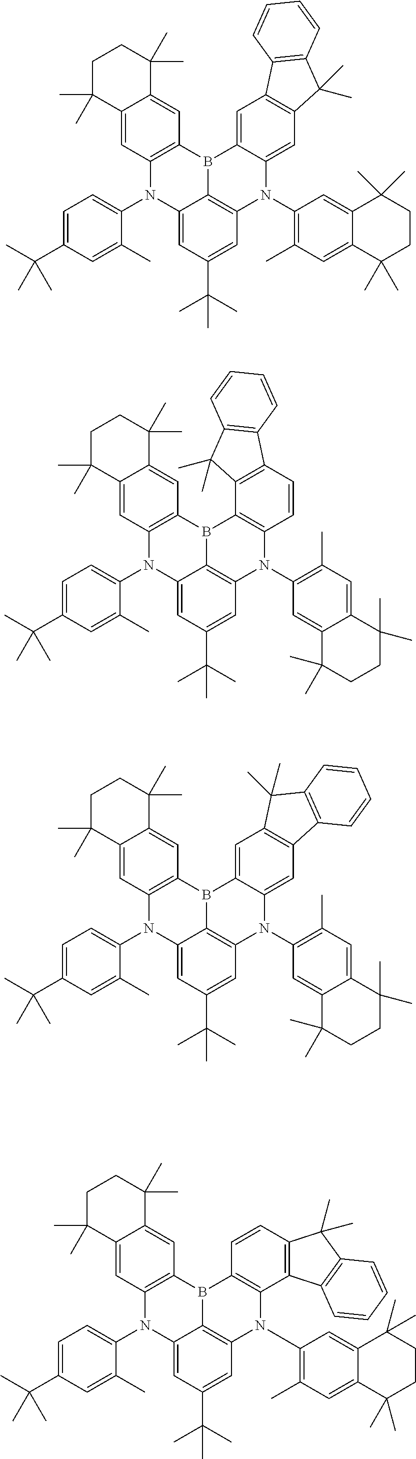

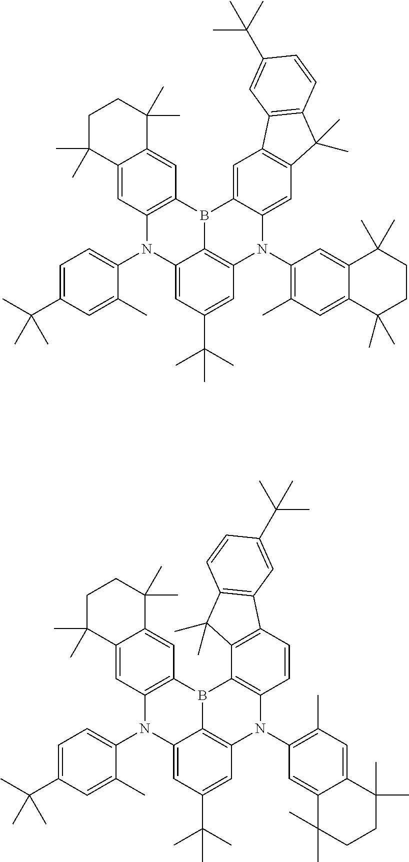 [SMILES: Cc1cc(C(C)(C)C)ccc1N1c2cc3c(cc2B2c4cc5c(cc4N(c4cc6c(cc4C)C(C)(C)CCC6(C)C)c4cc(C(C)(C)C)cc1c42)C(C)(C)c1ccc(C(C)(C)C)cc1-5)C(C)(C)CCC3(C)C ; Cc1cc(C(C)(C)C)ccc1N1c2cc3c(cc2B2c4c1cc(C(C)(C)C)cc4N(c1cc4c(cc1C)C(C)(C)CCC4(C)C)c1ccc4c(c12)C(C)(C)c1ccc(C(C)(C)C)cc1-4)C(C)(C)CCC3(C)C]

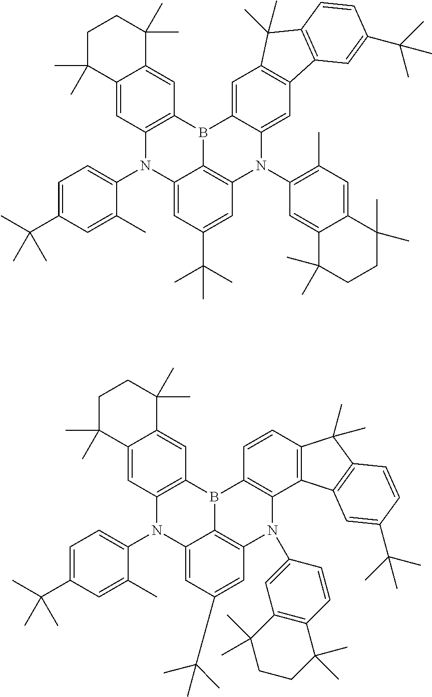

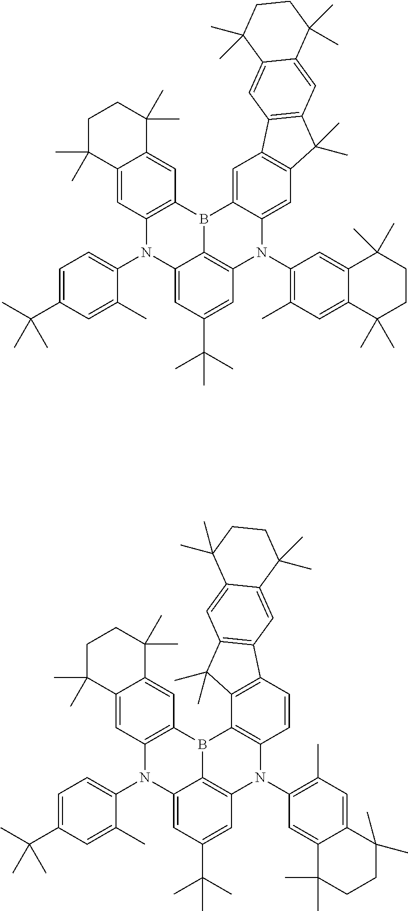 [SMILES: Cc1cc(C(C)(C)C)ccc1N1c2cc3c(cc2B2c4cc5c(cc4N(c4cc6c(cc4C)C(C)(C)CCC6(C)C)c4cc(C(C)(C)C)cc1c42)C(C)(C)c1cc2c(cc1-5)C(C)(C)CCC2(C)C)C(C)(C)CCC3(C)C ; Cc1cc(C(C)(C)C)ccc1N1c2cc3c(cc2B2c4c1cc(C(C)(C)C)cc4N(c1cc4c(cc1C)C(C)(C)CCC4(C)C)c1ccc4c(c12)C(C)(C)c1cc2c(cc1-4)C(C)(C)CCC2(C)C)C(C)(C)CCC3(C)C]

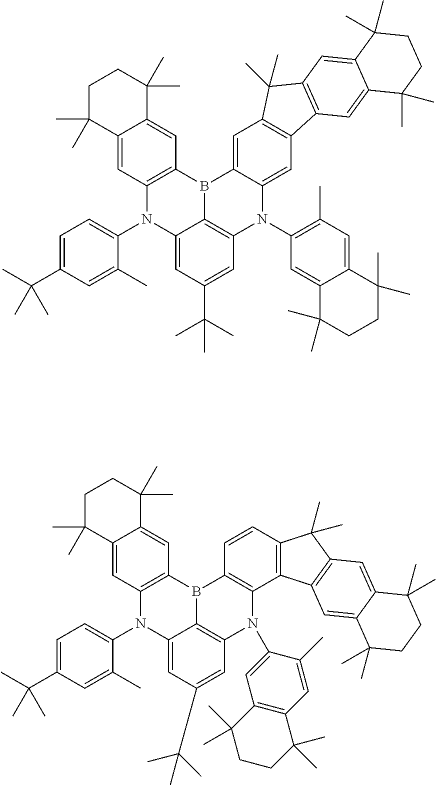

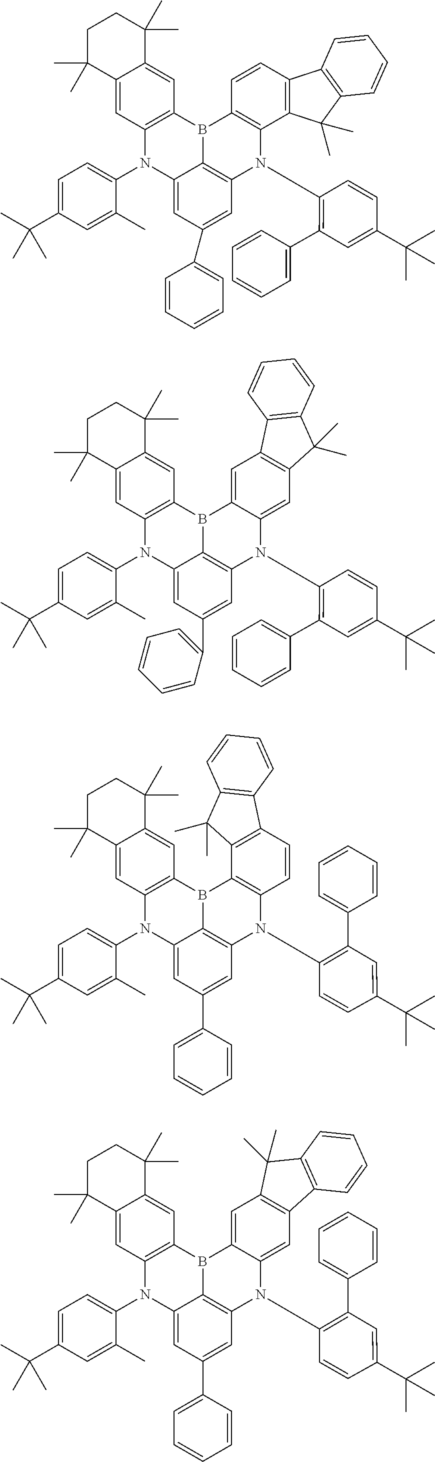

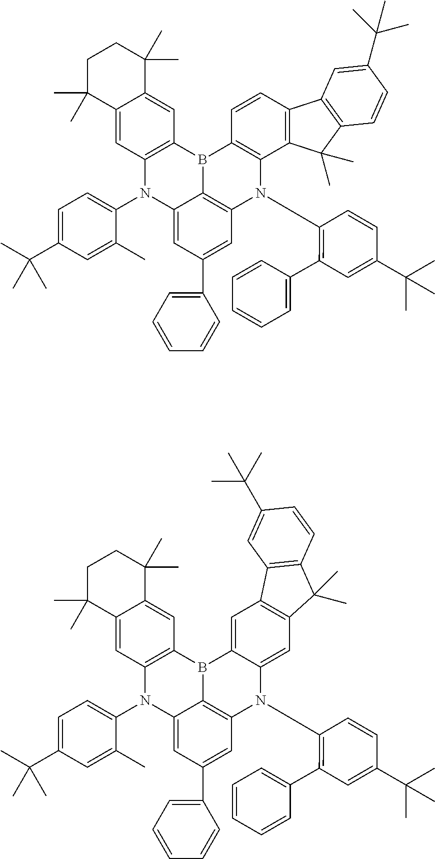

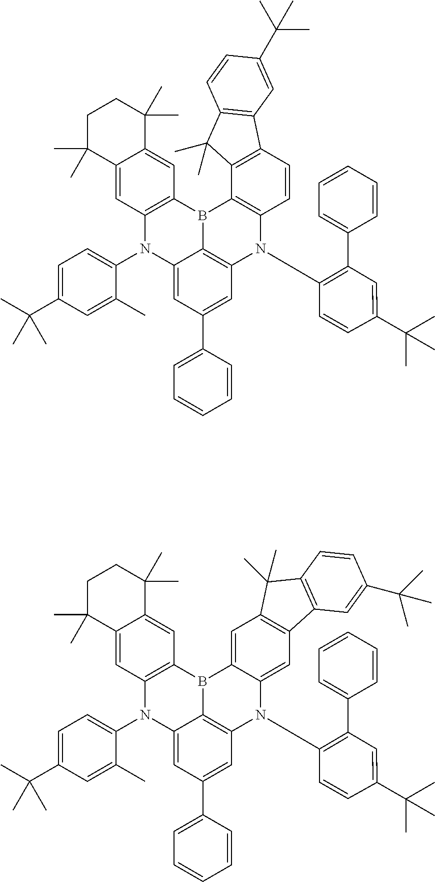

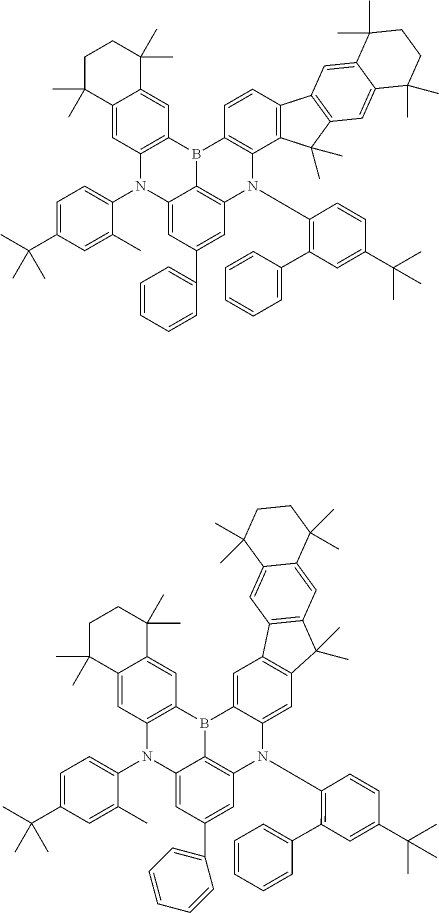

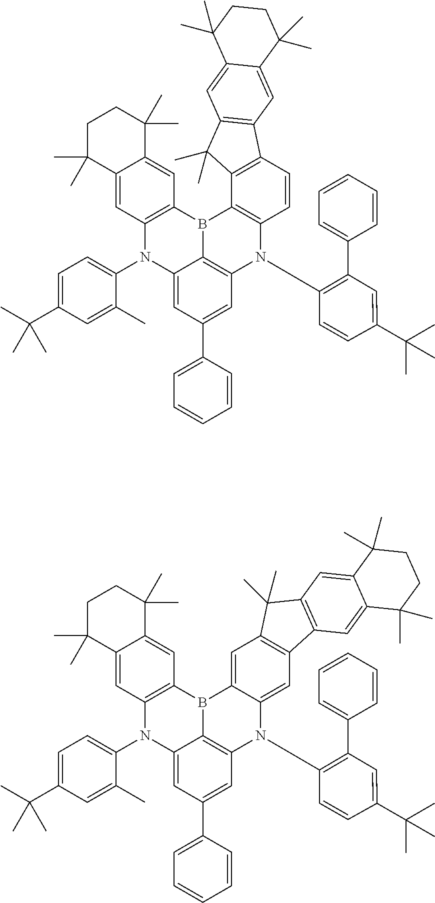

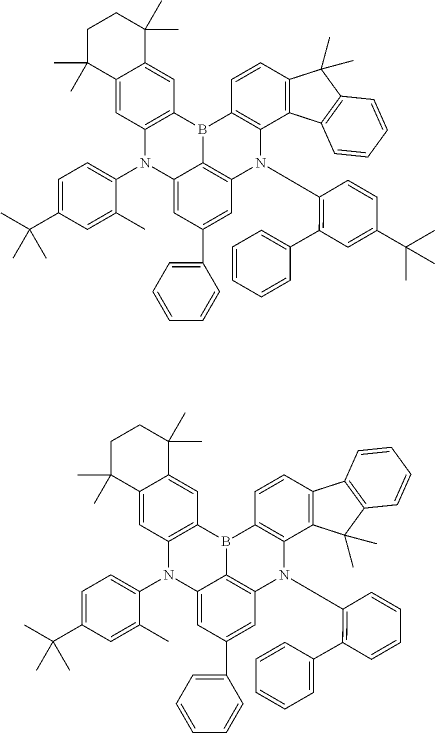

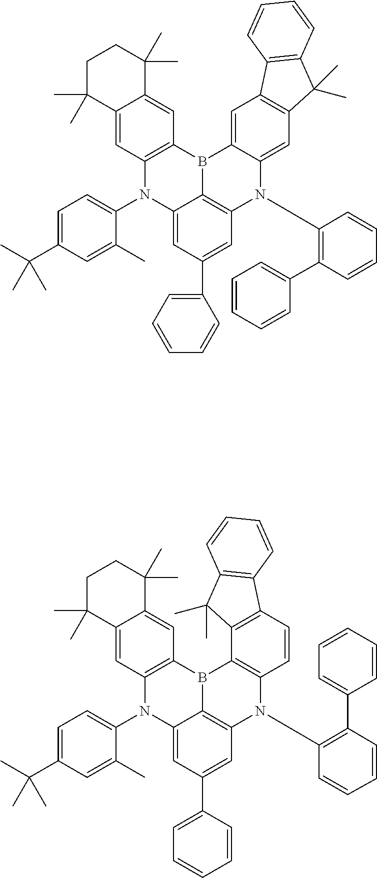 [SMILES: Cc1cc(C(C)(C)C)ccc1N1c2cc3c(cc2B2c4cc5c(cc4N(c4ccccc4-c4ccccc4)c4cc(-c6ccccc6)cc1c42)C(C)(C)c1ccccc1-5)C(C)(C)CCC3(C)C ; Cc1cc(C(C)(C)C)ccc1N1c2cc3c(cc2B2c4c1cc(-c1ccccc1)cc4N(c1ccccc1-c1ccccc1)c1ccc4c(c12)C(C)(C)c1ccccc1-4)C(C)(C)CCC3(C)C]

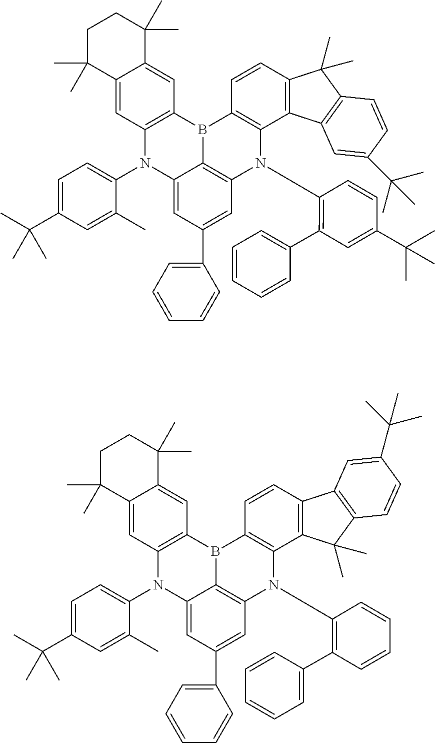

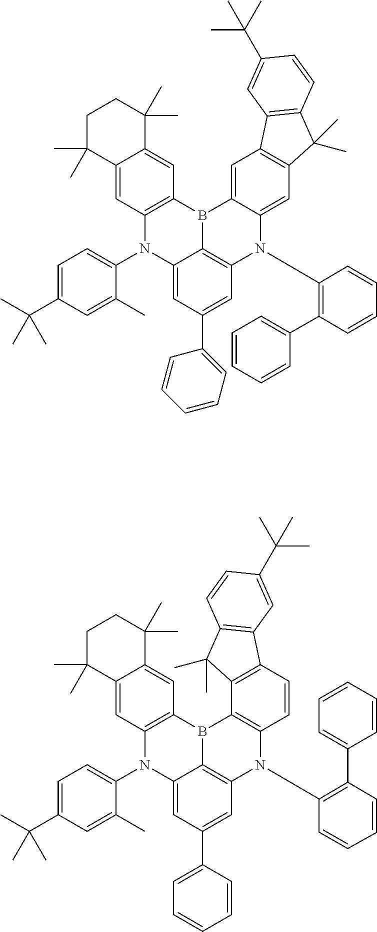 [SMILES: Cc1cc(C(C)(C)C)ccc1N1c2cc3c(cc2B2c4cc5c(cc4N(c4ccccc4-c4ccccc4)c4cc(-c6ccccc6)cc1c42)C(C)(C)c1ccc(C(C)(C)C)cc1-5)C(C)(C)CCC3(C)C ; Cc1cc(C(C)(C)C)ccc1N1c2cc3c(cc2B2c4c1cc(-c1ccccc1)cc4N(c1ccccc1-c1ccccc1)c1ccc4c(c12)C(C)(C)c1ccc(C(C)(C)C)cc1-4)C(C)(C)CCC3(C)C]

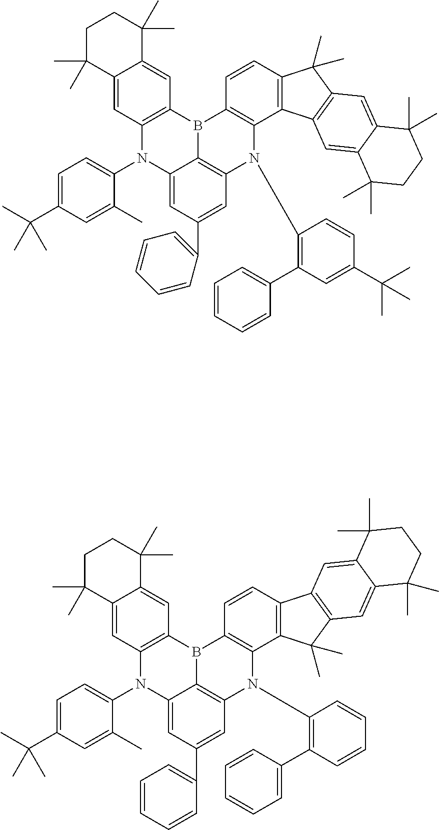

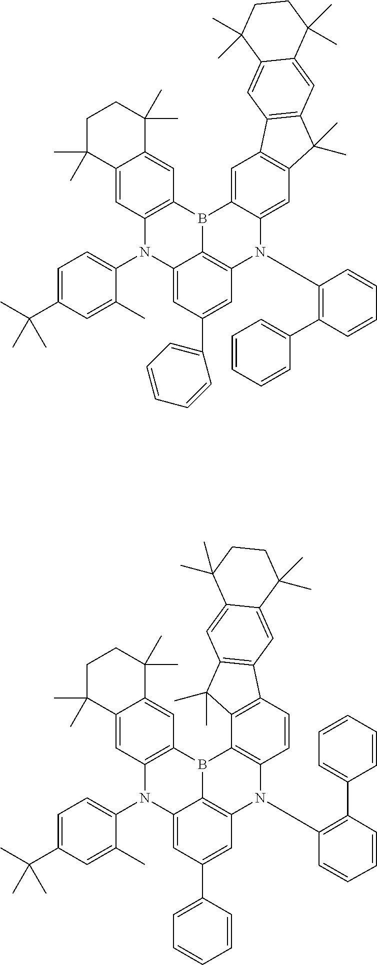 [SMILES: Cc1cc(C(C)(C)C)ccc1N1c2cc3c(cc2B2c4cc5c(cc4N(c4ccccc4-c4ccccc4)c4cc(-c6ccccc6)cc1c42)C(C)(C)c1cc2c(cc1-5)C(C)(C)CCC2(C)C)C(C)(C)CCC3(C)C ; Cc1cc(C(C)(C)C)ccc1N1c2cc3c(cc2B2c4c1cc(-c1ccccc1)cc4N(c1ccccc1-c1ccccc1)c1ccc4c(c12)C(C)(C)c1cc2c(cc1-4)C(C)(C)CCC2(C)C)C(C)(C)CCC3(C)C]

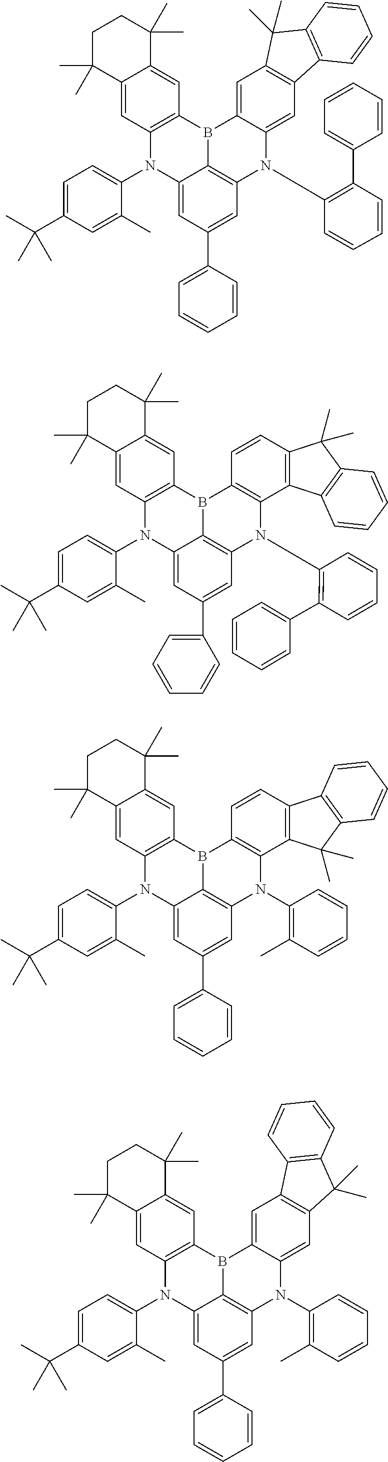

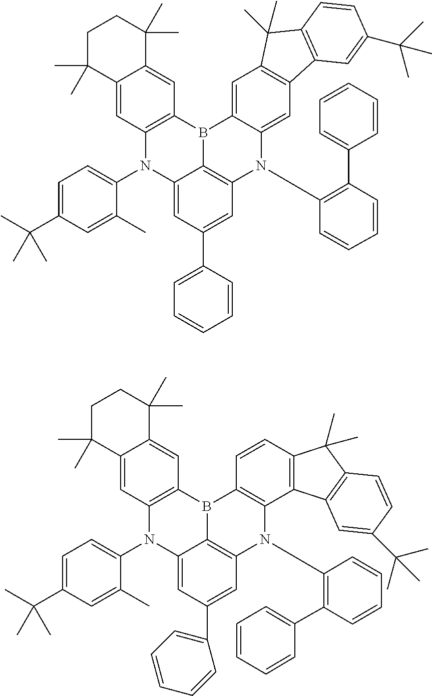

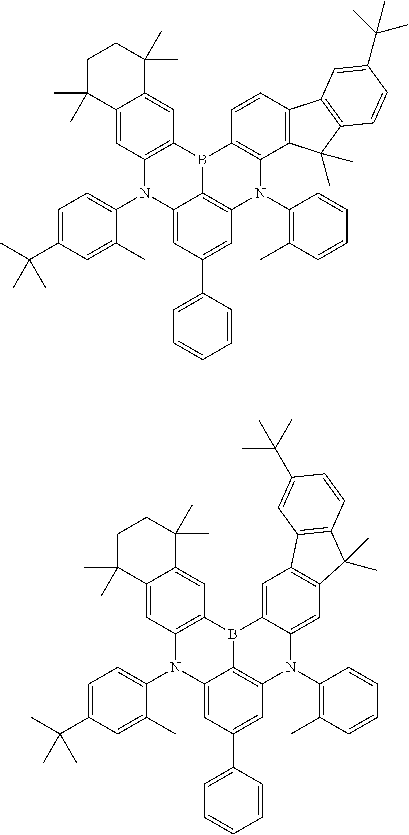

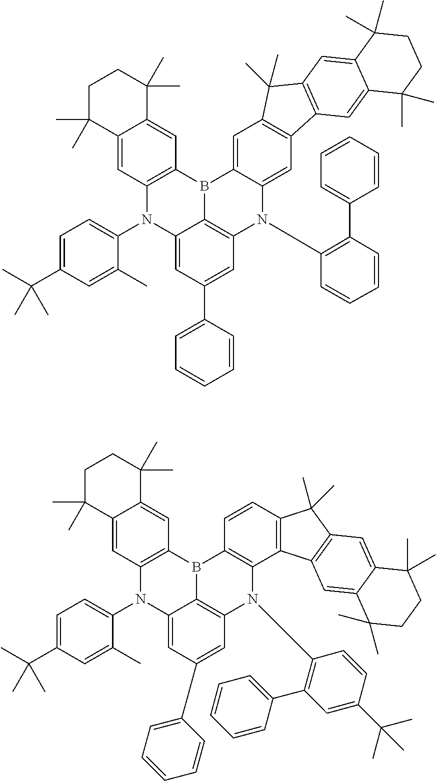

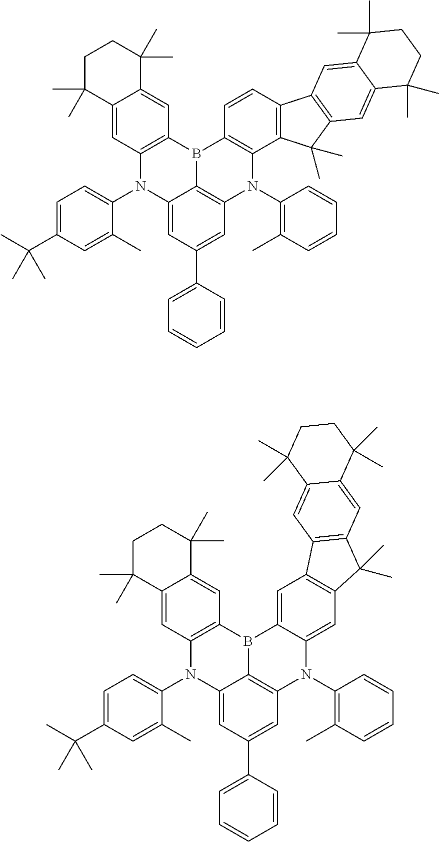

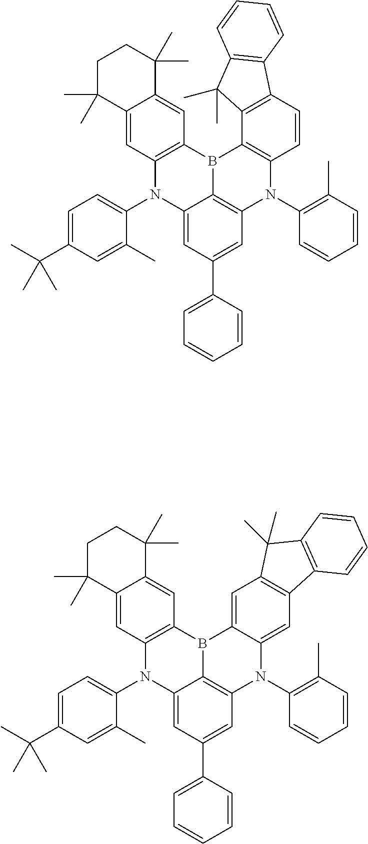 [SMILES: Cc1cc(C(C)(C)C)ccc1N1c2cc3c(cc2B2c4c1cc(-c1ccccc1)cc4N(c1ccccc1C)c1ccc4c(c12)C(C)(C)c1ccccc1-4)C(C)(C)CCC3(C)C ; Cc1ccccc1N1c2cc3c(cc2B2c4cc5c(cc4N(c4ccc(C(C)(C)C)cc4C)c4cc(-c6ccccc6)cc1c42)C(C)(C)CCC5(C)C)C(C)(C)c1ccccc1-3]

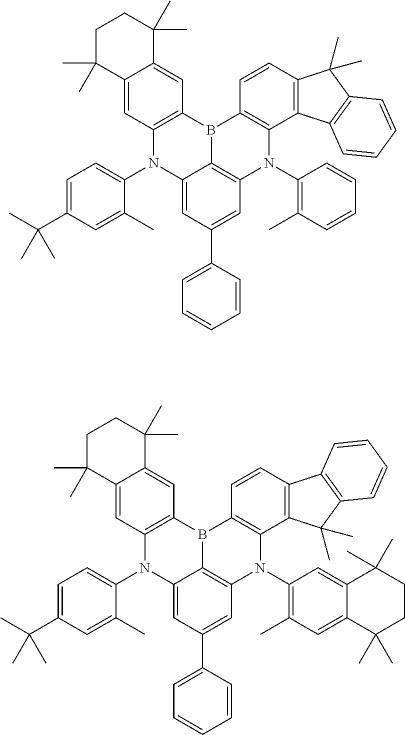 [SMILES: Cc1cc(C(C)(C)C)ccc1N1c2cc3c(cc2B2c4ccc5c(c4N(c4ccccc4C)c4cc(-c6ccccc6)cc1c42)-c1ccccc1C5(C)C)C(C)(C)CCC3(C)C ; Cc1cc(C(C)(C)C)ccc1N1c2cc3c(cc2B2c4ccc5c(c4N(c4cc6c(cc4C)C(C)(C)CCC6(C)C)c4cc(-c6ccccc6)cc1c42)C(C)(C)c1ccccc1-5)C(C)(C)CCC3(C)C]

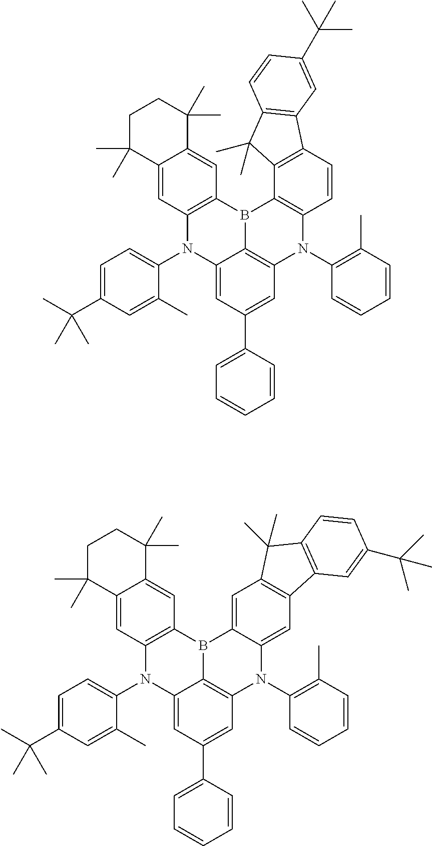 [SMILES: Cc1cc(C(C)(C)C)ccc1N1c2cc3c(cc2B2c4c1cc(-c1ccccc1)cc4N(c1ccccc1C)c1ccc4c(c12)C(C)(C)c1ccc(C(C)(C)C)cc1-4)C(C)(C)CCC3(C)C ; Cc1ccccc1N1c2cc3c(cc2B2c4cc5c(cc4N(c4ccc(C(C)(C)C)cc4C)c4cc(-c6ccccc6)cc1c42)C(C)(C)CCC5(C)C)C(C)(C)c1ccc(C(C)(C)C)cc1-3]

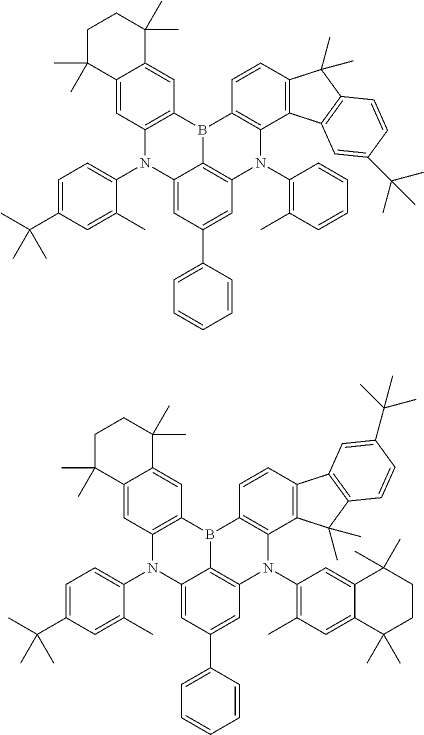

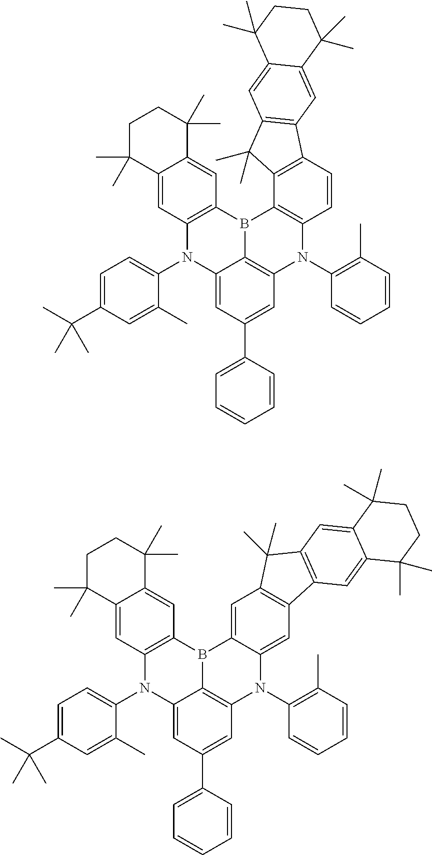 [SMILES: Cc1cc(C(C)(C)C)ccc1N1c2cc3c(cc2B2c4c1cc(-c1ccccc1)cc4N(c1ccccc1C)c1ccc4c(c12)C(C)(C)c1cc2c(cc1-4)C(C)(C)CCC2(C)C)C(C)(C)CCC3(C)C ; Cc1ccccc1N1c2cc3c(cc2B2c4cc5c(cc4N(c4ccc(C(C)(C)C)cc4C)c4cc(-c6ccccc6)cc1c42)C(C)(C)CCC5(C)C)C(C)(C)c1cc2c(cc1-3)C(C)(C)CCC2(C)C]

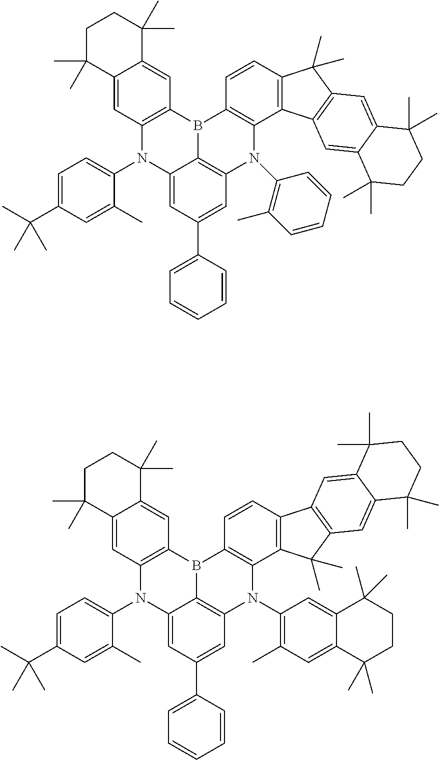

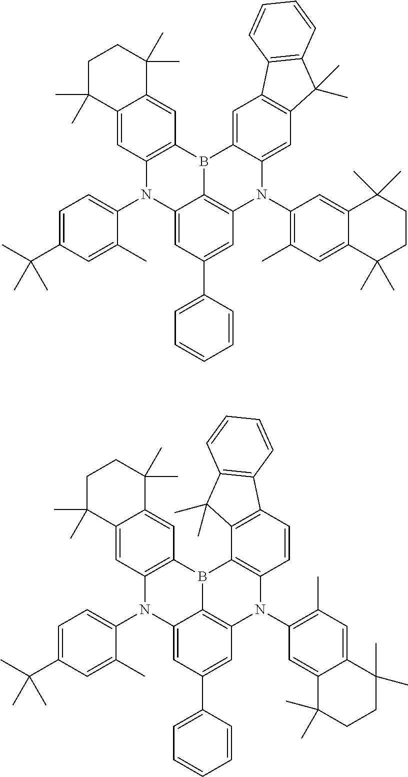 [SMILES: Cc1cc(C(C)(C)C)ccc1N1c2cc3c(cc2B2c4cc5c(cc4N(c4cc6c(cc4C)C(C)(C)CCC6(C)C)c4cc(-c6ccccc6)cc1c42)C(C)(C)c1ccccc1-5)C(C)(C)CCC3(C)C ; Cc1cc(C(C)(C)C)ccc1N1c2cc3c(cc2B2c4c1cc(-c1ccccc1)cc4N(c1cc4c(cc1C)C(C)(C)CCC4(C)C)c1ccc4c(c12)C(C)(C)c1ccccc1-4)C(C)(C)CCC3(C)C]

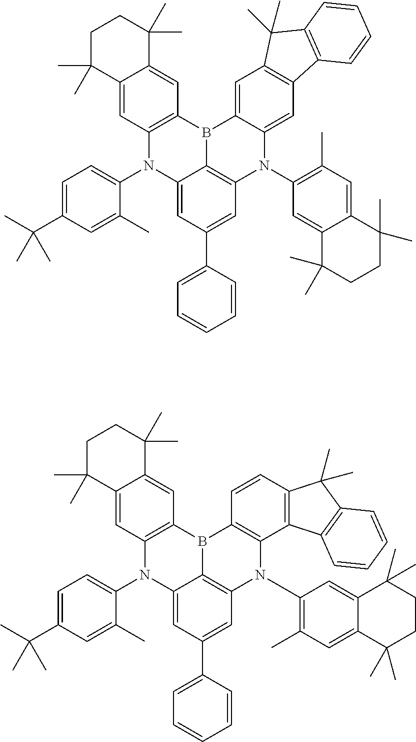

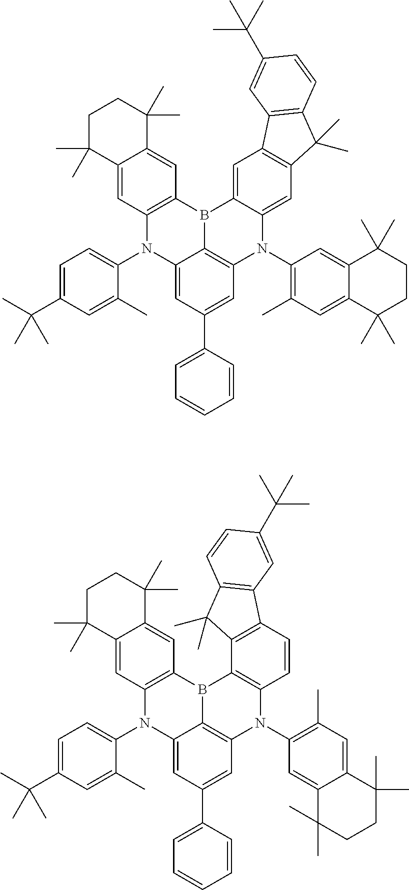 [SMILES: Cc1cc(C(C)(C)C)ccc1N1c2cc3c(cc2B2c4cc5c(cc4N(c4cc6c(cc4C)C(C)(C)CCC6(C)C)c4cc(-c6ccccc6)cc1c42)C(C)(C)c1ccc(C(C)(C)C)cc1-5)C(C)(C)CCC3(C)C ; Cc1cc(C(C)(C)C)ccc1N1c2cc3c(cc2B2c4c1cc(-c1ccccc1)cc4N(c1cc4c(cc1C)C(C)(C)CCC4(C)C)c1ccc4c(c12)C(C)(C)c1ccc(C(C)(C)C)cc1-4)C(C)(C)CCC3(C)C]

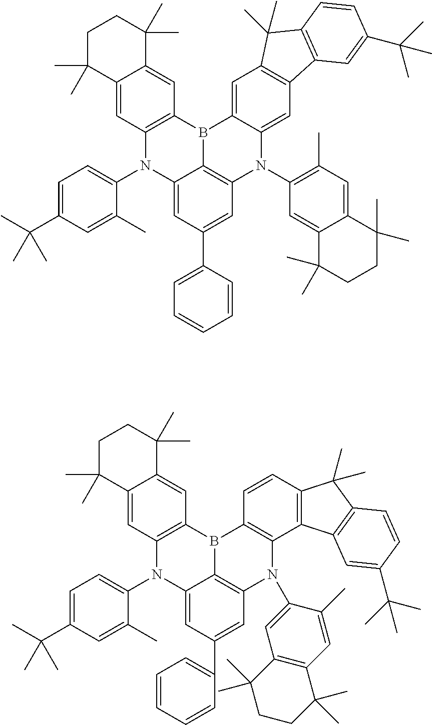

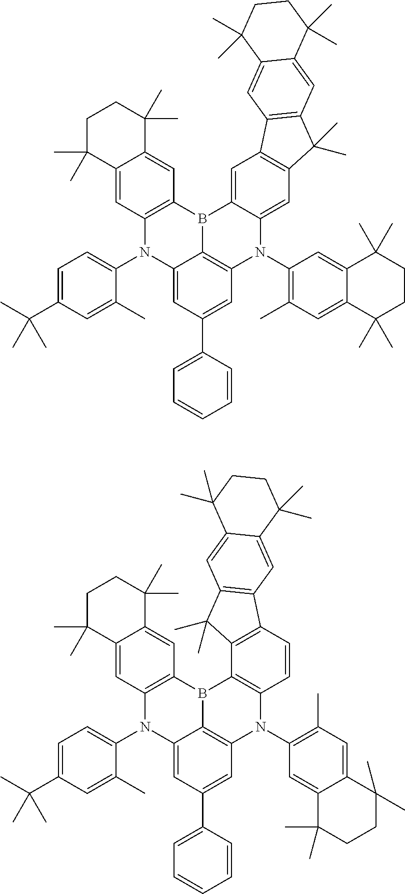 [SMILES: Cc1cc(C(C)(C)C)ccc1N1c2cc3c(cc2B2c4cc5c(cc4N(c4cc6c(cc4C)C(C)(C)CCC6(C)C)c4cc(-c6ccccc6)cc1c42)C(C)(C)c1cc2c(cc1-5)C(C)(C)CCC2(C)C)C(C)(C)CCC3(C)C ; Cc1cc(C(C)(C)C)ccc1N1c2cc3c(cc2B2c4c1cc(-c1ccccc1)cc4N(c1cc4c(cc1C)C(C)(C)CCC4(C)C)c1ccc4c(c12)C(C)(C)c1cc2c(cc1-4)C(C)(C)CCC2(C)C)C(C)(C)CCC3(C)C]

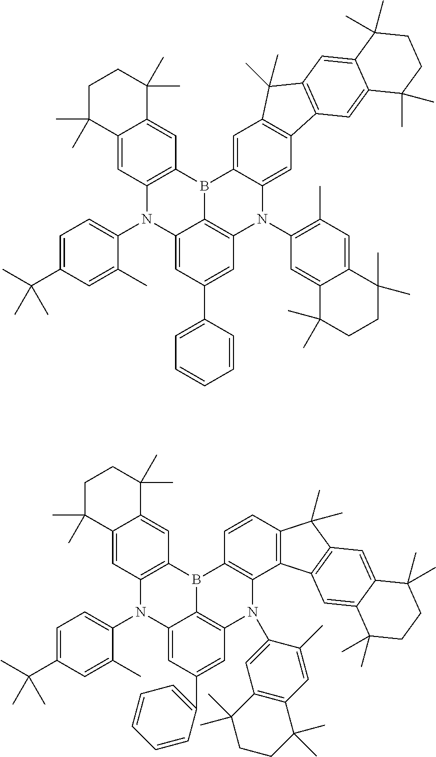

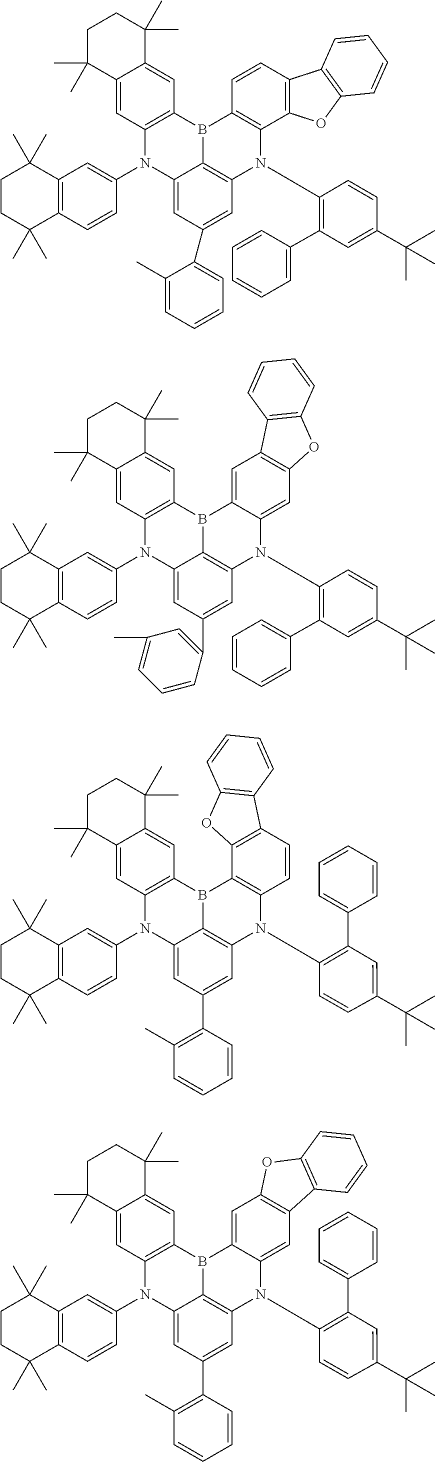

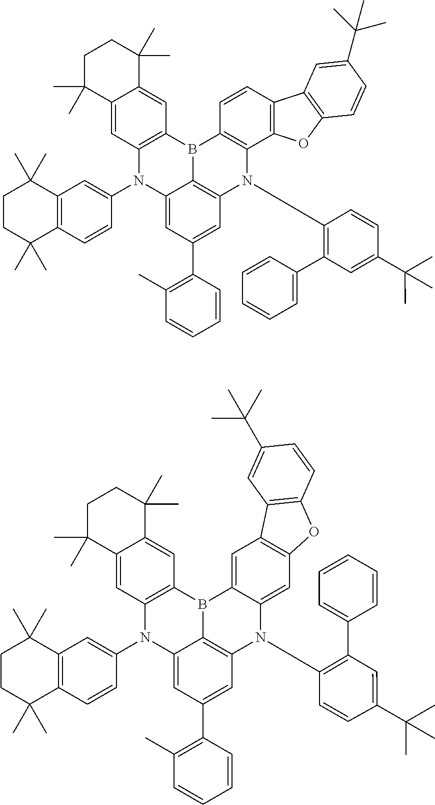 [SMILES: Cc1ccccc1-c1cc2c3c(c1)N(c1ccc(C(C)(C)C)cc1-c1ccccc1)c1c(ccc4c1oc1ccc(C(C)(C)C)cc14)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4oc5ccc(C(C)(C)C)cc5c4cc1B3c1cc3c(cc1N2c1ccc2c(c1)C(C)(C)CCC2(C)C)C(C)(C)CCC3(C)C]

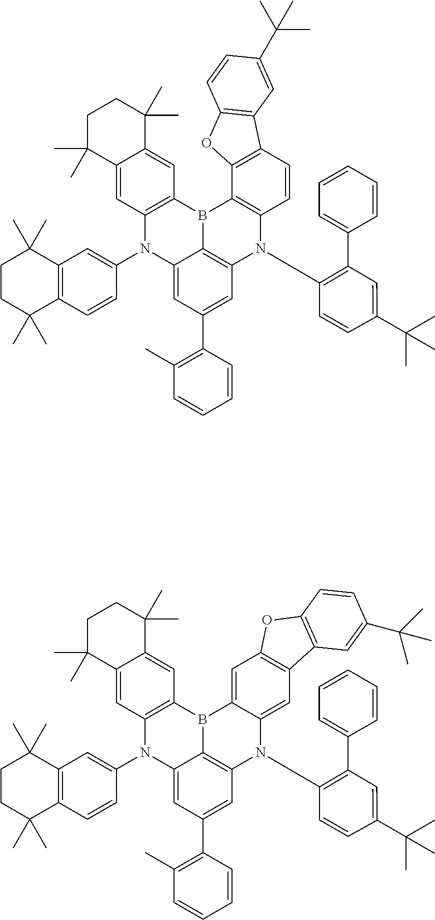 [SMILES: Cc1ccccc1-c1cc2c3c(c1)N(c1ccc(C(C)(C)C)cc1-c1ccccc1)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14]

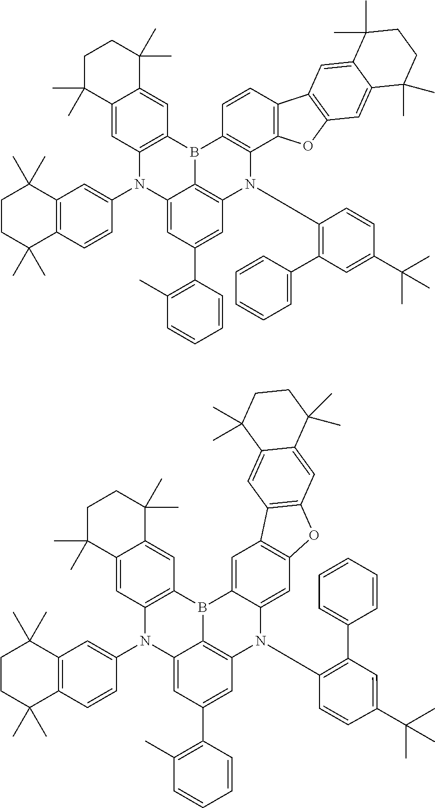 [SMILES: Cc1ccccc1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C]

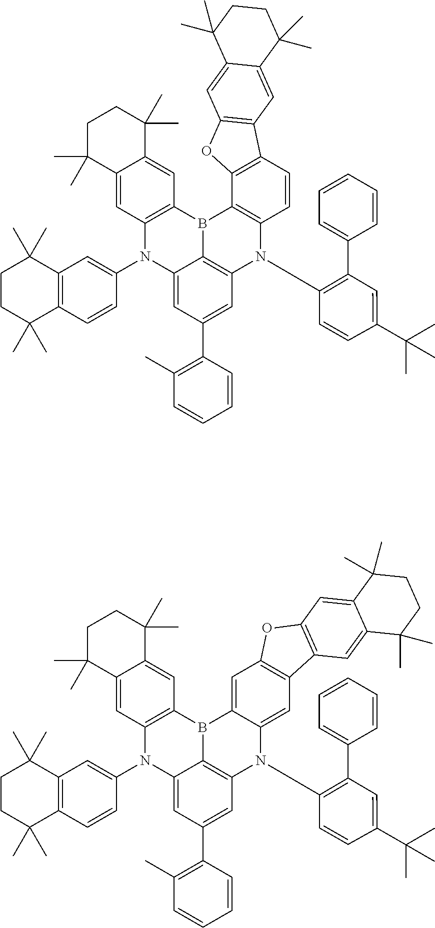 [SMILES: Cc1ccccc1-c1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1cc2c(cc14)C(C)(C)CCC2(C)C]

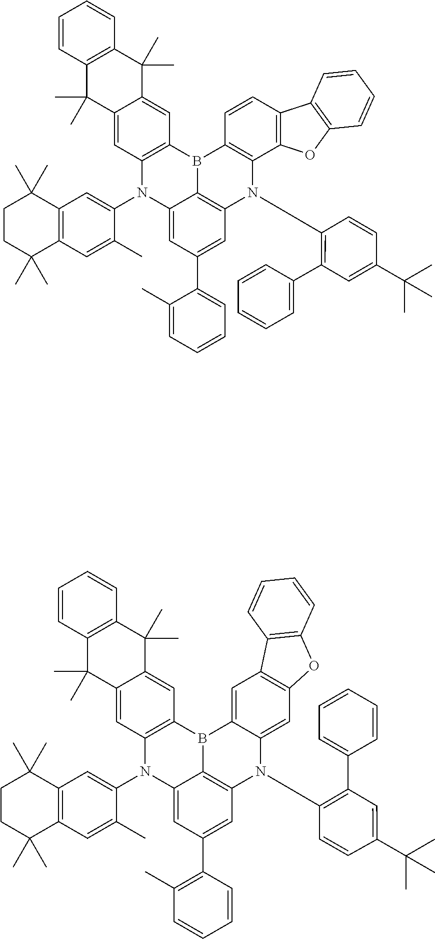 [SMILES: Cc1ccccc1-c1cc2c3c(c1)N(c1ccc(C(C)(C)C)cc1-c1ccccc1)c1c(ccc4c1oc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4oc5ccccc5c4cc1B3c1cc3c(cc1N2c1cc2c(cc1C)C(C)(C)CCC2(C)C)C(C)(C)c1ccccc1C3(C)C]

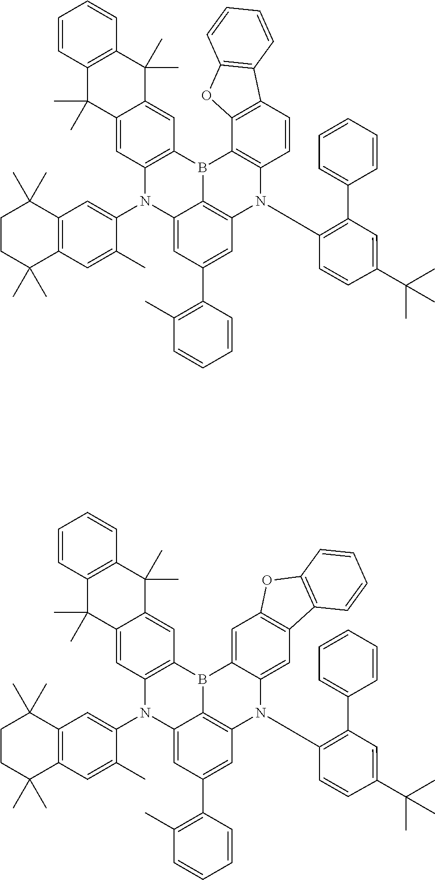 [SMILES: Cc1ccccc1-c1cc2c3c(c1)N(c1ccc(C(C)(C)C)cc1-c1ccccc1)c1ccc4c(oc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1ccccc14]

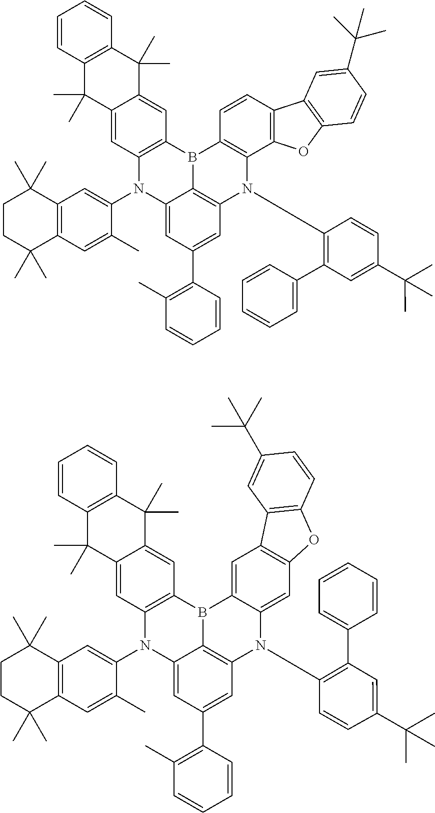 [SMILES: Cc1ccccc1-c1cc2c3c(c1)N(c1ccc(C(C)(C)C)cc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C]

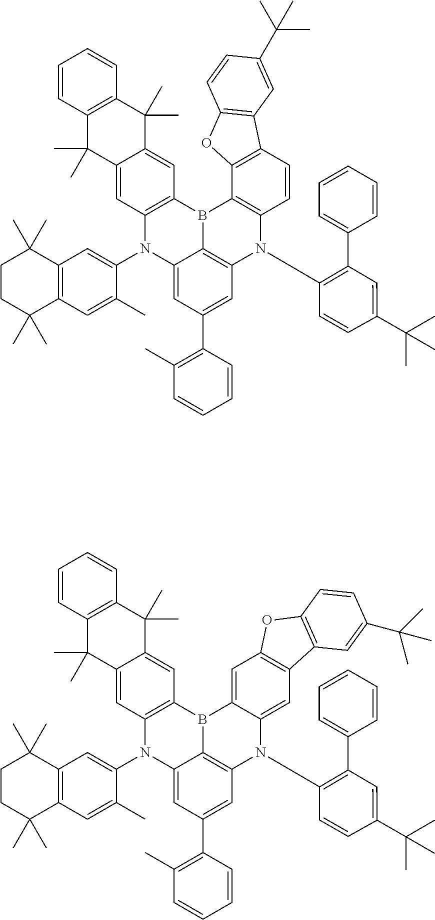 [SMILES: Cc1ccccc1-c1cc2c3c(c1)N(c1ccc(C(C)(C)C)cc1-c1ccccc1)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14]

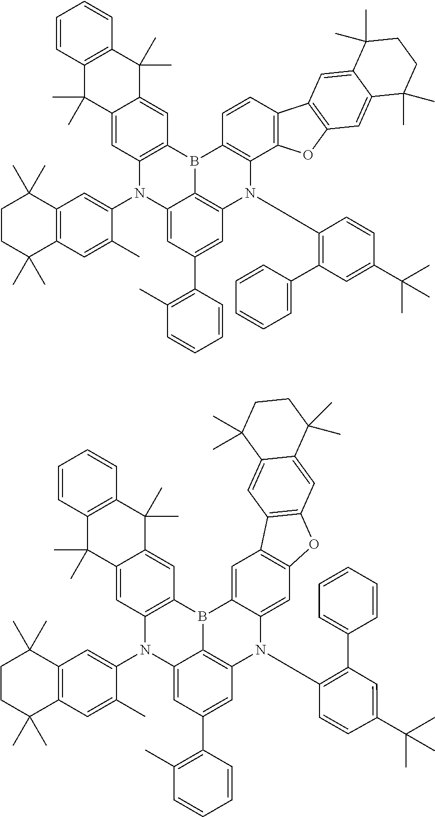 [SMILES: Cc1ccccc1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

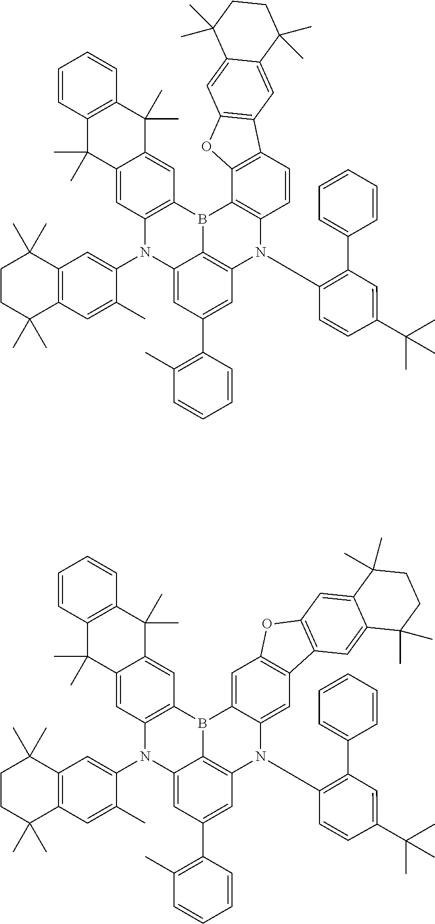 [SMILES: Cc1ccccc1-c1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C]

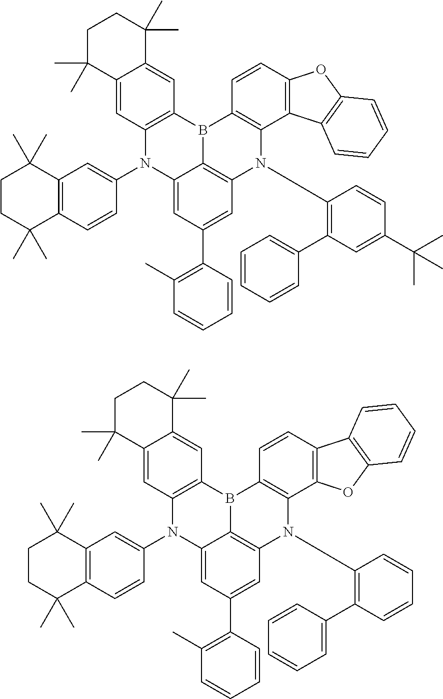

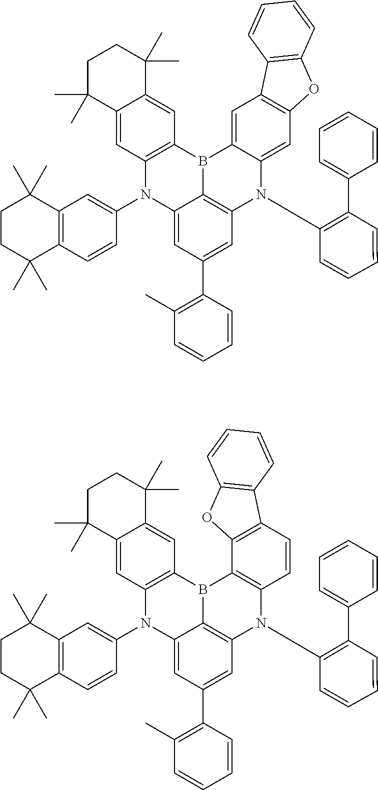 [SMILES: Cc1ccccc1-c1cc2c3c(c1)N(c1ccccc1-c1ccccc1)c1cc4oc5ccccc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1ccc4c(oc5ccccc54)c1B3c1cc3c(cc1N2c1ccc2c(c1)C(C)(C)CCC2(C)C)C(C)(C)CCC3(C)C]

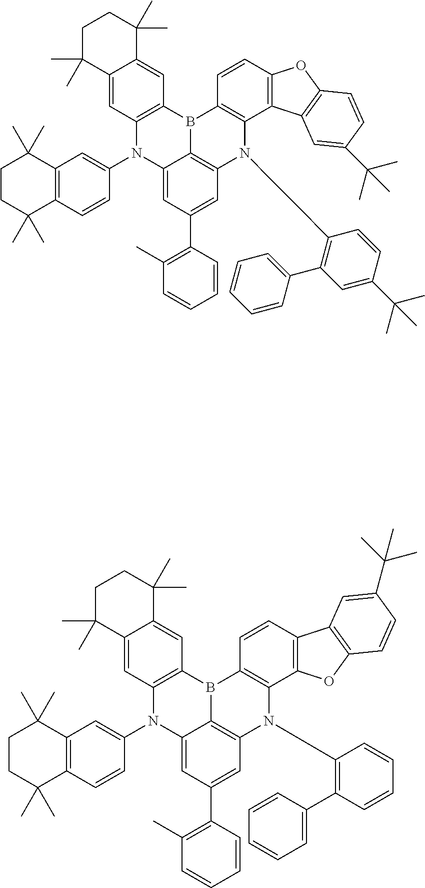 [SMILES: Cc1ccccc1-c1cc2c3c(c1)N(c1ccc(C(C)(C)C)cc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1oc1ccc(C(C)(C)C)cc14)B3c1cc3c(cc1N2c1ccc2c(c1)C(C)(C)CCC2(C)C)C(C)(C)CCC3(C)C]

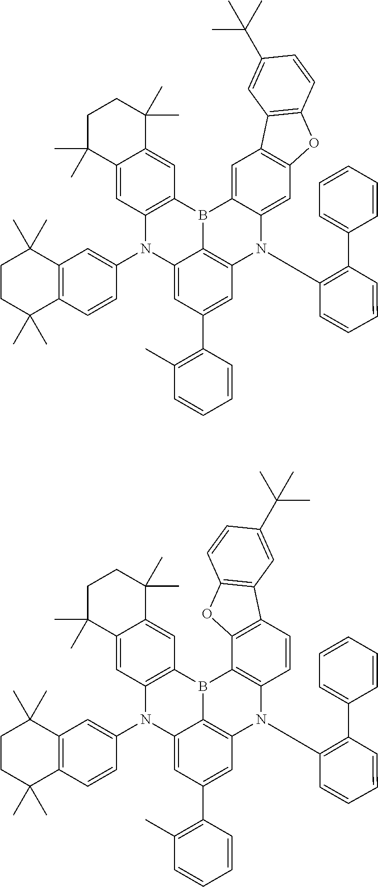 [SMILES: Cc1ccccc1-c1cc2c3c(c1)N(c1ccccc1-c1ccccc1)c1cc4oc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1ccc4c(oc5ccc(C(C)(C)C)cc54)c1B3c1cc3c(cc1N2c1ccc2c(c1)C(C)(C)CCC2(C)C)C(C)(C)CCC3(C)C]

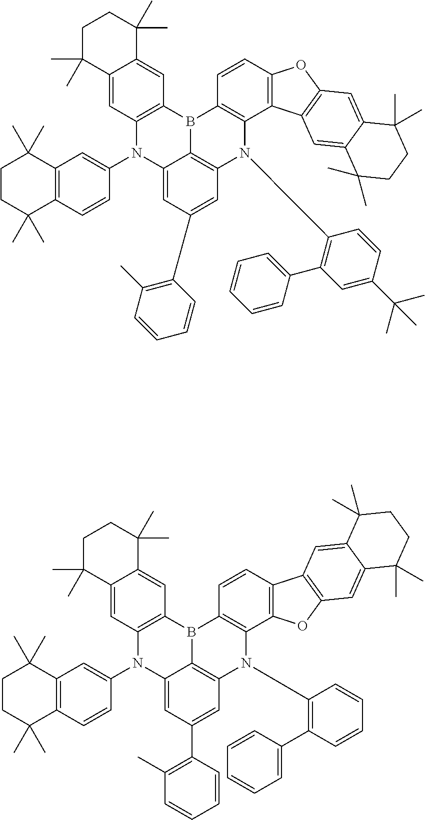 [SMILES: Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C]

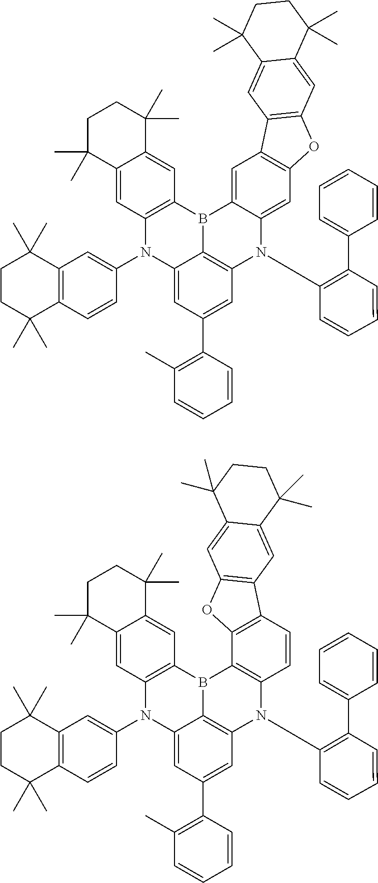

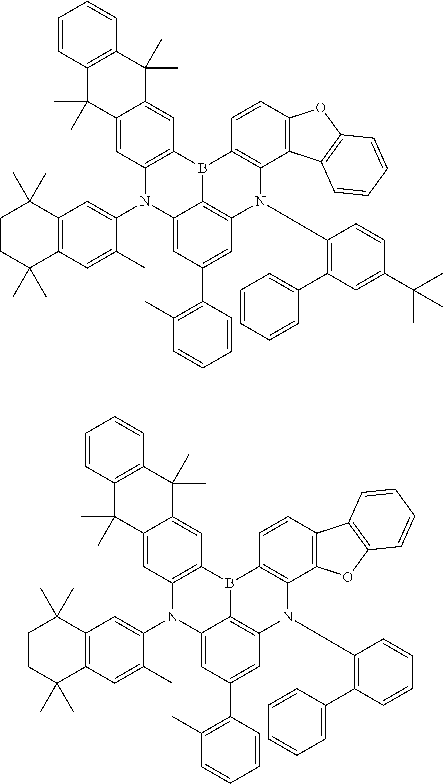 [SMILES: Cc1ccccc1-c1cc2c3c(c1)N(c1ccc(C(C)(C)C)cc1-c1ccccc1)c1c(ccc4oc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1oc1ccccc14)B3c1cc3c(cc1N2c1cc2c(cc1C)C(C)(C)CCC2(C)C)C(C)(C)c1ccccc1C3(C)C]

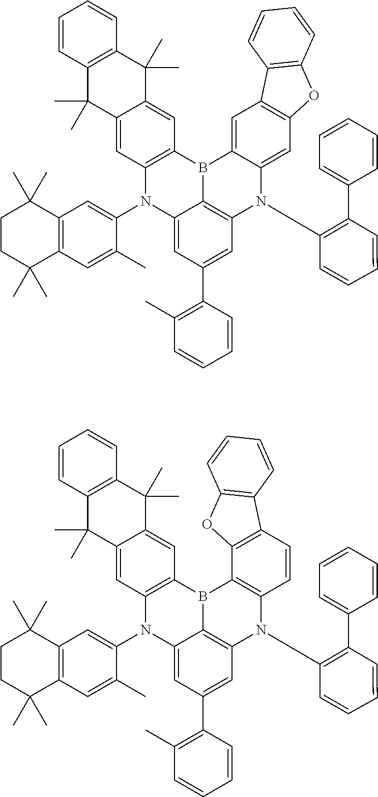 [SMILES: Cc1ccccc1-c1cc2c3c(c1)N(c1ccccc1-c1ccccc1)c1cc4oc5ccccc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1ccc4c(oc5ccccc54)c1B3c1cc3c(cc1N2c1cc2c(cc1C)C(C)(C)CCC2(C)C)C(C)(C)c1ccccc1C3(C)C]

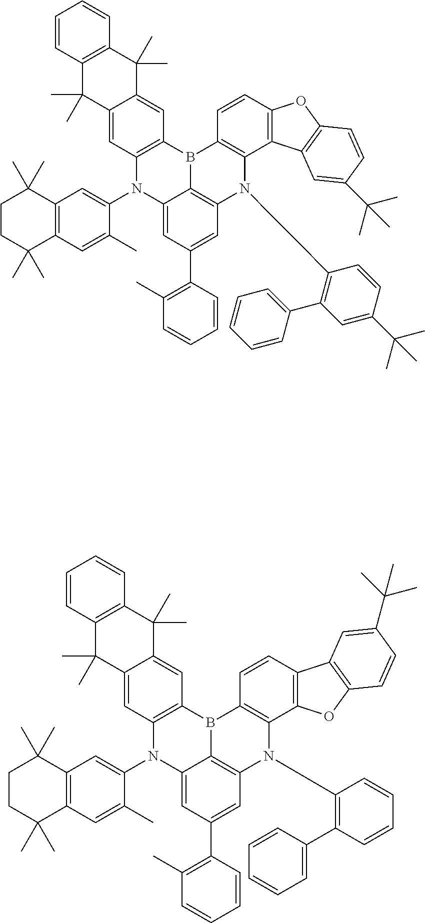 [SMILES: Cc1ccccc1-c1cc2c3c(c1)N(c1ccc(C(C)(C)C)cc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C]

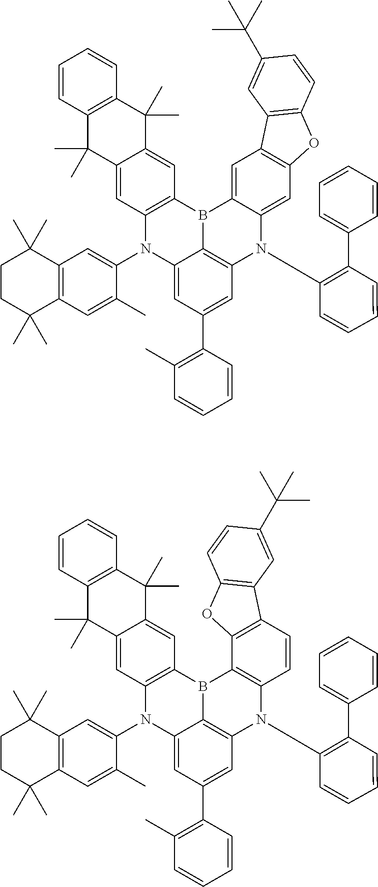 [SMILES: Cc1ccccc1-c1cc2c3c(c1)N(c1ccccc1-c1ccccc1)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C]

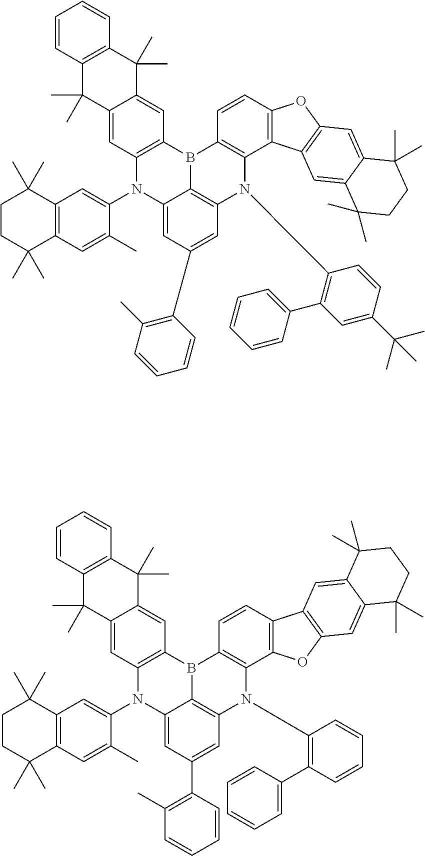 [SMILES: Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

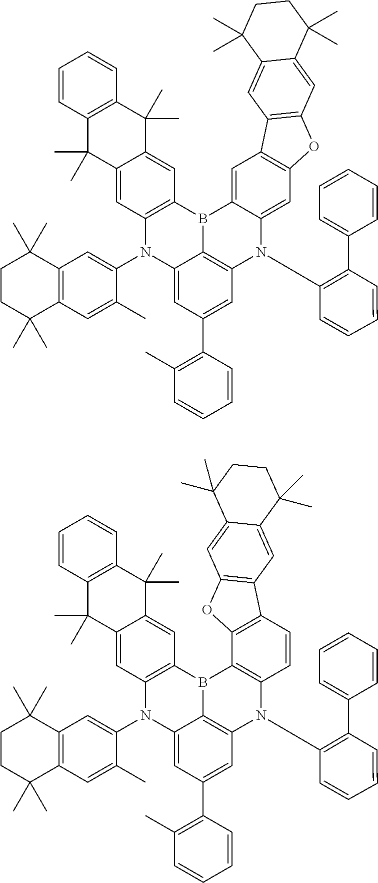

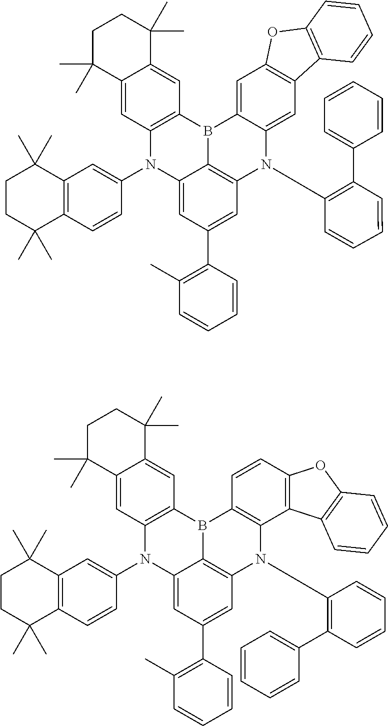 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccccc14 ; Cc1ccccc1-c1cc2c3c(c1)N(c1ccccc1-c1ccccc1)c1c(ccc4oc5ccccc5c14)B3c1cc3c(cc1N2c1ccc2c(c1)C(C)(C)CCC2(C)C)C(C)(C)CCC3(C)C]

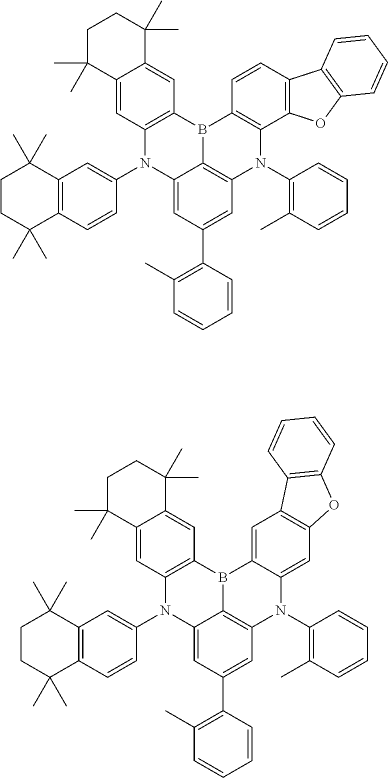 [SMILES: Cc1ccccc1-c1cc2c3c(c1)N(c1ccccc1C)c1c(ccc4c1oc1ccccc14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4oc5ccccc5c4cc1B3c1cc3c(cc1N2c1ccc2c(c1)C(C)(C)CCC2(C)C)C(C)(C)CCC3(C)C]

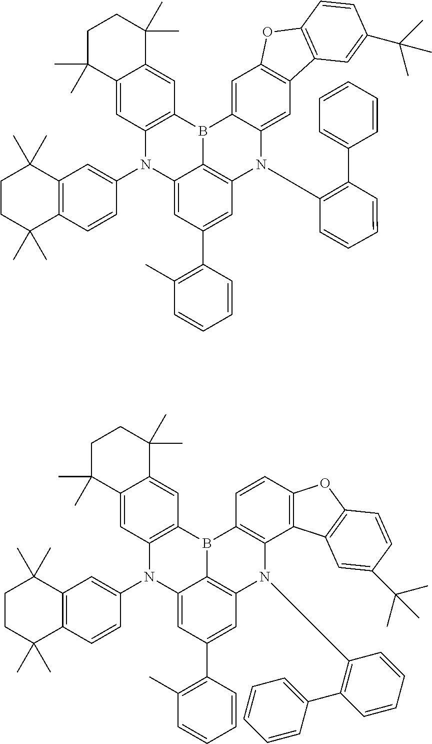 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1ccccc1-c1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C]

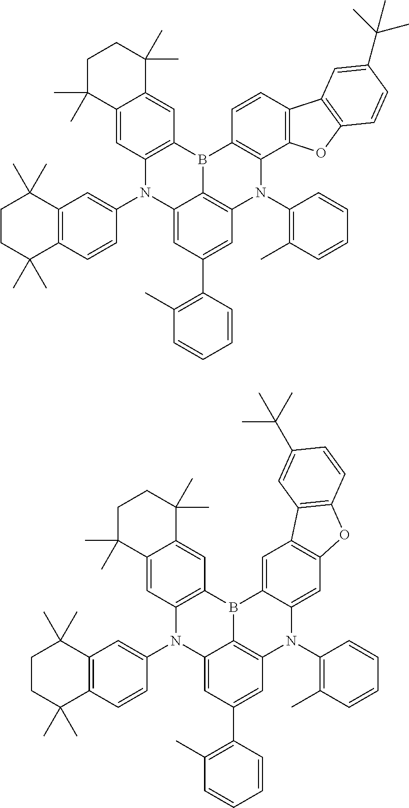 [SMILES: Cc1ccccc1-c1cc2c3c(c1)N(c1ccccc1C)c1c(ccc4c1oc1ccc(C(C)(C)C)cc14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4oc5ccc(C(C)(C)C)cc5c4cc1B3c1cc3c(cc1N2c1ccc2c(c1)C(C)(C)CCC2(C)C)C(C)(C)CCC3(C)C]

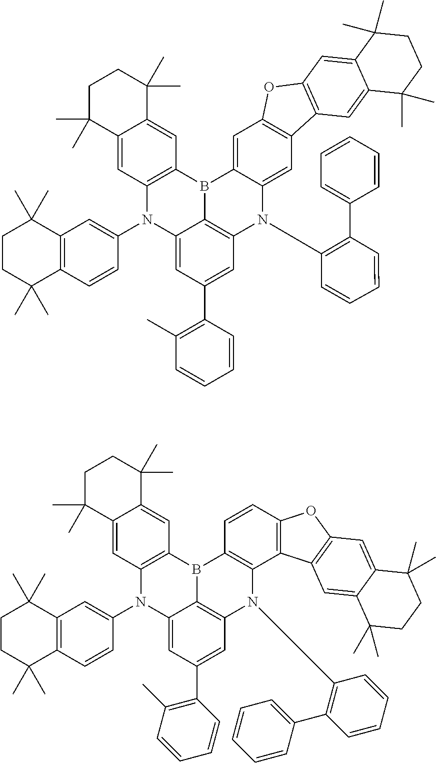 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)oc1cc2c(cc14)C(C)(C)CCC2(C)C ; Cc1ccccc1-c1cc2c3c(c1)N(c1ccccc1-c1ccccc1)c1c(ccc4oc5cc6c(cc5c14)C(C)(C)CCC6(C)C)B3c1cc3c(cc1N2c1ccc2c(c1)C(C)(C)CCC2(C)C)C(C)(C)CCC3(C)C]

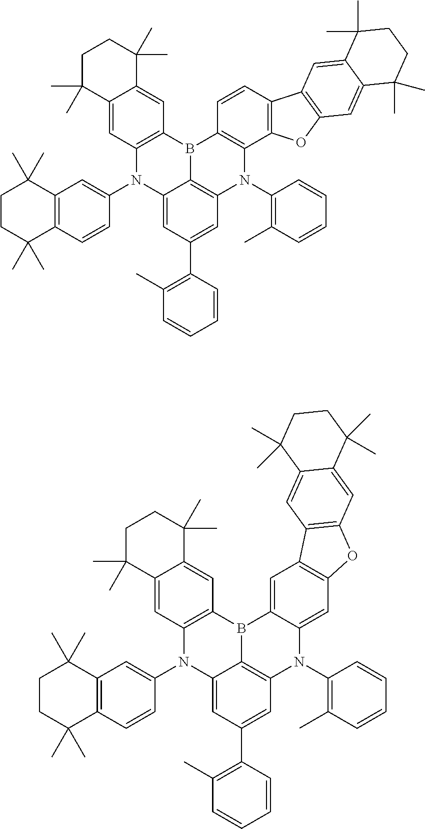 [SMILES: Cc1ccccc1-c1cc2c3c(c1)N(c1ccccc1C)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4oc5cc6c(cc5c4cc1B3c1cc3c(cc1N2c1ccc2c(c1)C(C)(C)CCC2(C)C)C(C)(C)CCC3(C)C)C(C)(C)CCC6(C)C]

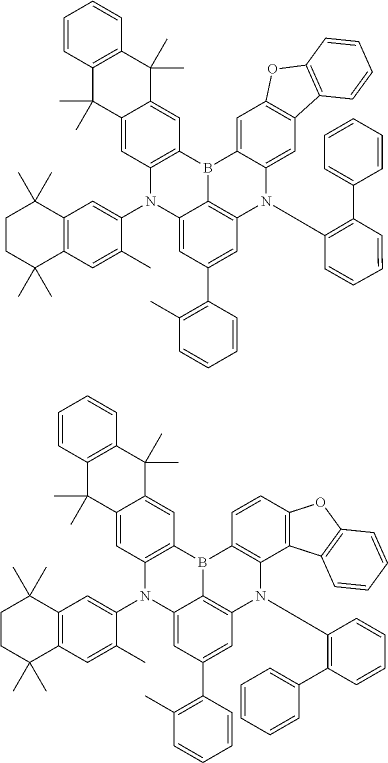 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1ccccc14 ; Cc1ccccc1-c1cc2c3c(c1)N(c1ccccc1-c1ccccc1)c1c(ccc4oc5ccccc5c14)B3c1cc3c(cc1N2c1cc2c(cc1C)C(C)(C)CCC2(C)C)C(C)(C)c1ccccc1C3(C)C]

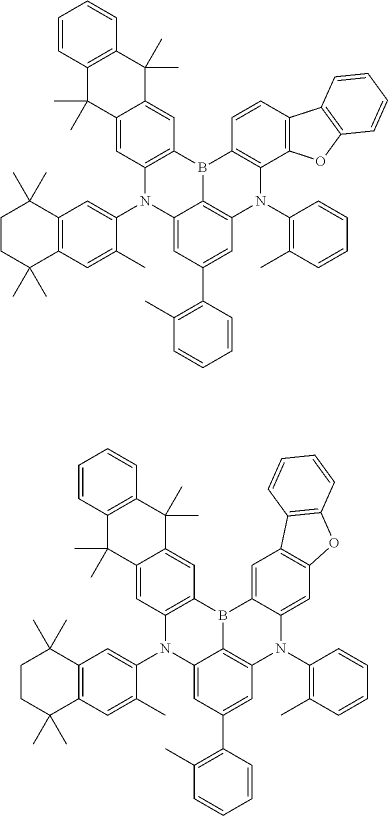 [SMILES: Cc1ccccc1-c1cc2c3c(c1)N(c1ccccc1C)c1c(ccc4c1oc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4oc5ccccc5c4cc1B3c1cc3c(cc1N2c1cc2c(cc1C)C(C)(C)CCC2(C)C)C(C)(C)c1ccccc1C3(C)C]

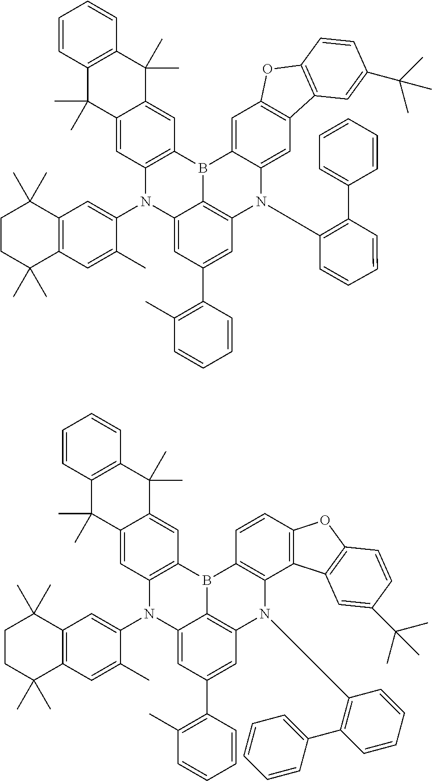 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1ccccc1-c1cc2c3c(c1)N(c1ccccc1-c1ccccc1)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C]

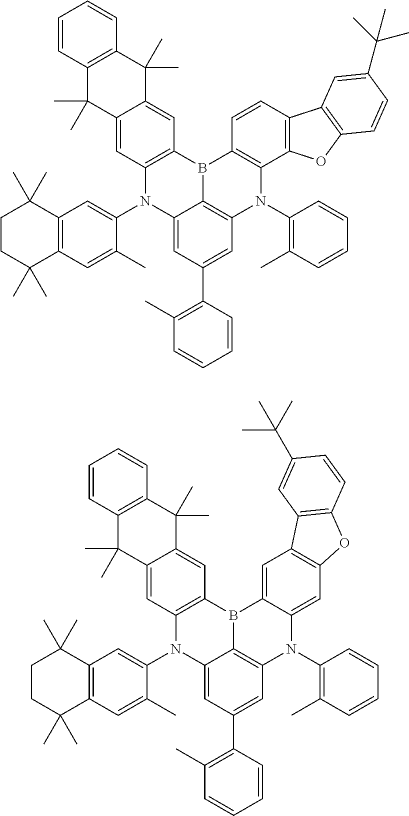 [SMILES: Cc1ccccc1-c1cc2c3c(c1)N(c1ccccc1C)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C]

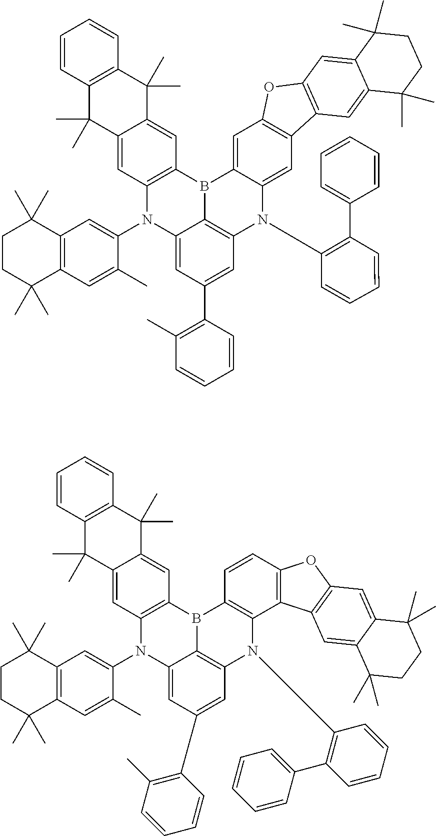 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C ; Cc1ccccc1-c1cc2c3c(c1)N(c1ccccc1-c1ccccc1)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C]

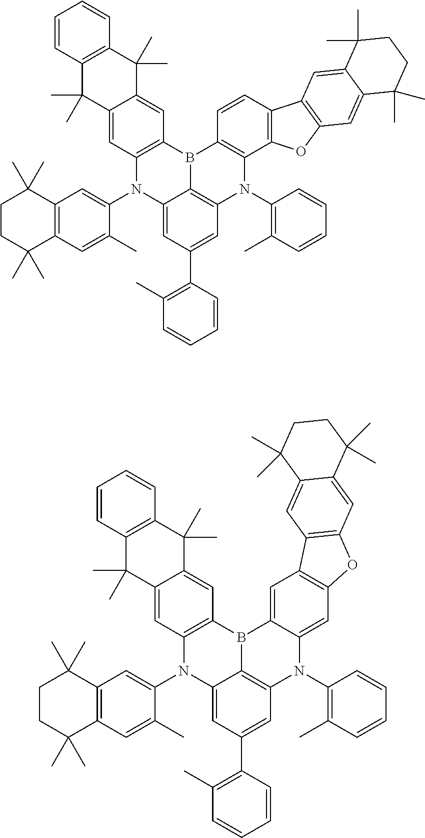 [SMILES: Cc1ccccc1-c1cc2c3c(c1)N(c1ccccc1C)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4oc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

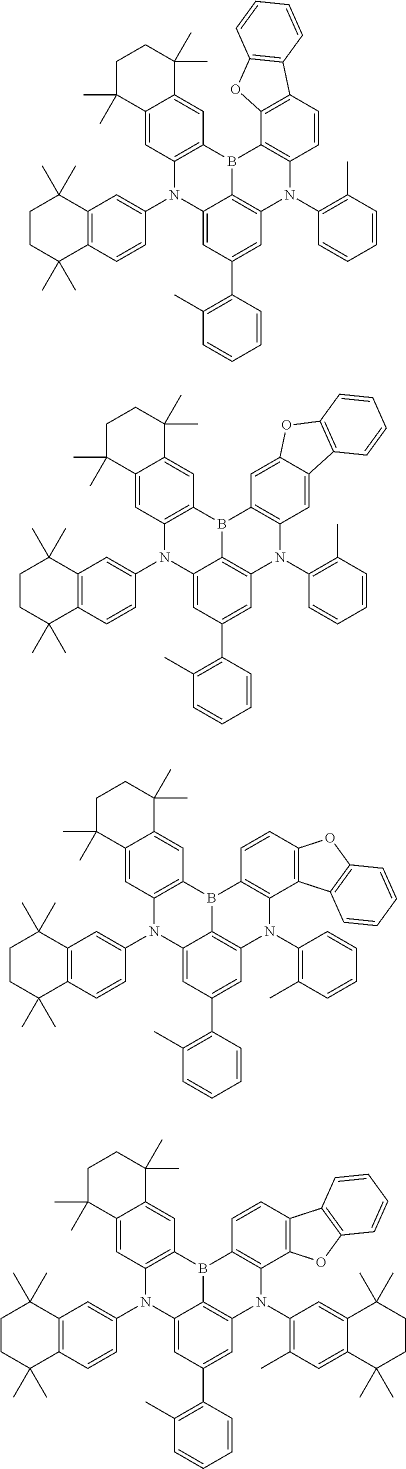 [SMILES: Cc1ccccc1-c1cc2c3c(c1)N(c1ccccc1C)c1ccc4c(oc5ccccc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1ccccc14 ; Cc1ccccc1-c1cc2c3c(c1)N(c1ccccc1C)c1c(ccc4oc5ccccc5c14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1c(ccc4c1oc1ccccc14)B3c1cc3c(cc1N2c1ccc2c(c1)C(C)(C)CCC2(C)C)C(C)(C)CCC3(C)C]

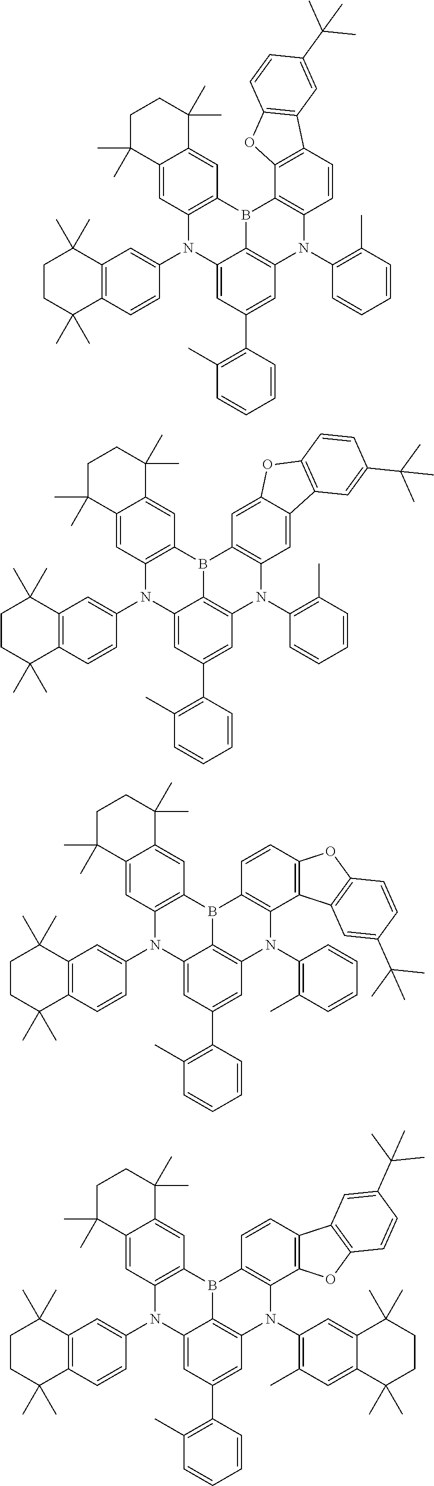

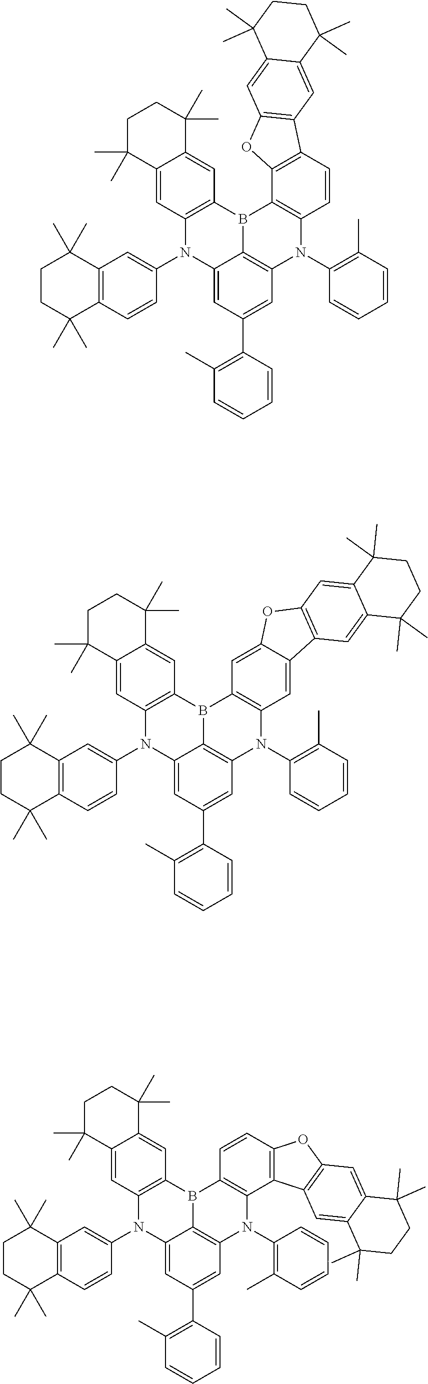 [SMILES: Cc1ccccc1-c1cc2c3c(c1)N(c1ccccc1C)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4c(cc1B3c1cc3c(cc1N2c1ccc2c(c1)C(C)(C)CCC2(C)C)C(C)(C)CCC3(C)C)oc1cc2c(cc14)C(C)(C)CCC2(C)C ; Cc1ccccc1-c1cc2c3c(c1)N(c1ccccc1C)c1c(ccc4oc5cc6c(cc5c14)C(C)(C)CCC6(C)C)B3c1cc3c(cc1N2c1ccc2c(c1)C(C)(C)CCC2(C)C)C(C)(C)CCC3(C)C]

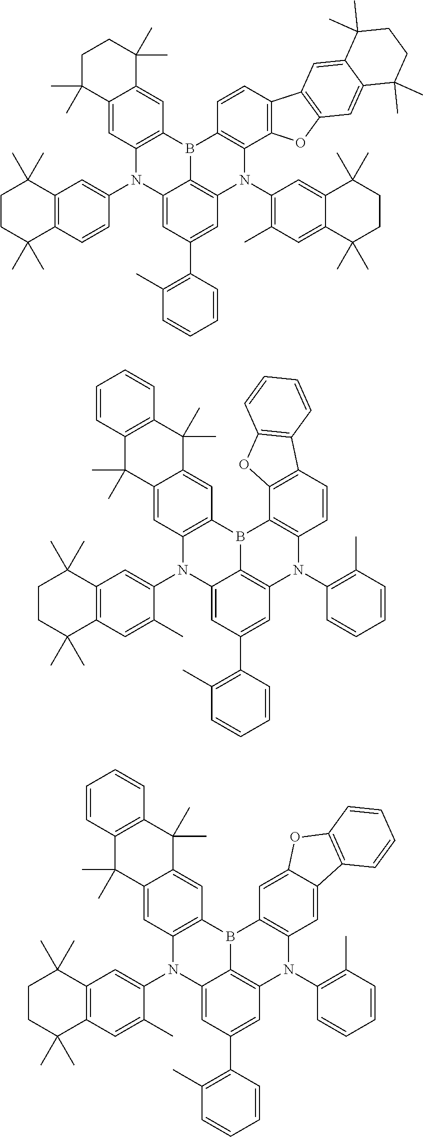 [SMILES: Cc1ccccc1-c1cc2c3c(c1)N(c1cc4c(cc1C)C(C)(C)CCC4(C)C)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1ccc4c(oc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1ccccc14]

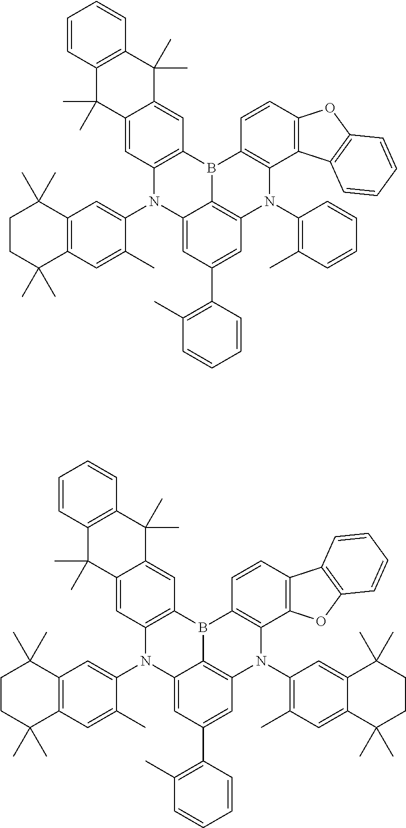 [SMILES: Cc1ccccc1-c1cc2c3c(c1)N(c1ccccc1C)c1c(ccc4oc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1oc1ccccc14)B3c1cc3c(cc1N2c1cc2c(cc1C)C(C)(C)CCC2(C)C)C(C)(C)c1ccccc1C3(C)C]

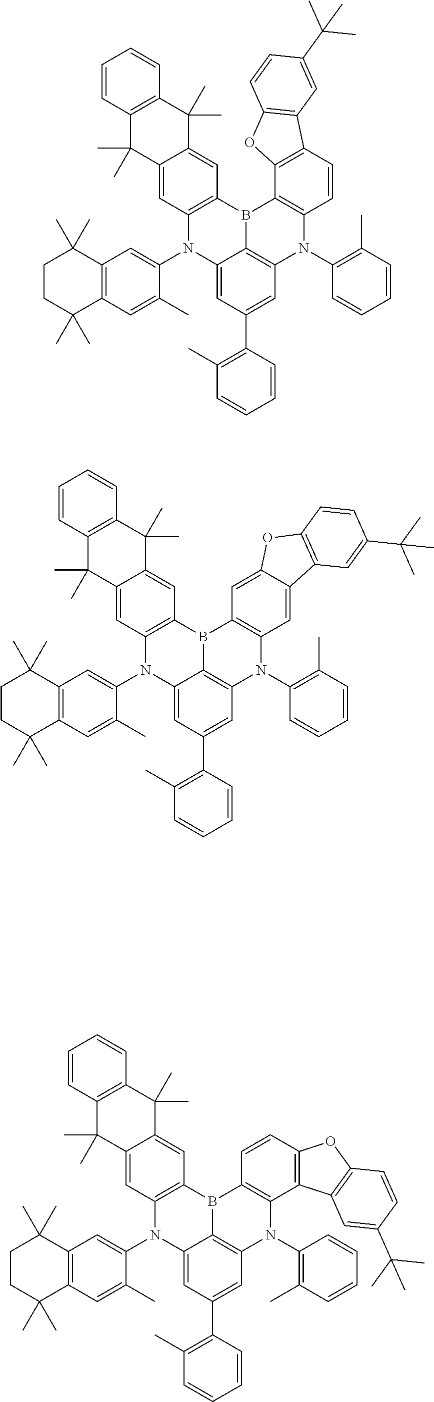 [SMILES: Cc1ccccc1-c1cc2c3c(c1)N(c1ccccc1C)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14 ; Cc1ccccc1-c1cc2c3c(c1)N(c1ccccc1C)c1c(ccc4oc5ccc(C(C)(C)C)cc5c14)B3c1cc3c(cc1N2c1cc2c(cc1C)C(C)(C)CCC2(C)C)C(C)(C)c1ccccc1C3(C)C]

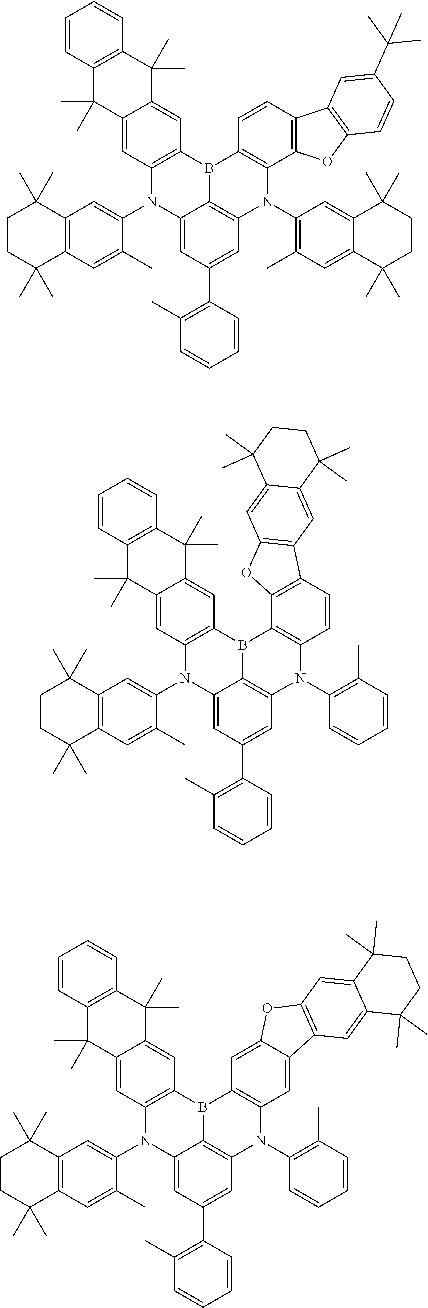 [SMILES: Cc1ccccc1-c1cc2c3c(c1)N(c1cc4c(cc1C)C(C)(C)CCC4(C)C)c1c(ccc4c1oc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1ccc4c(oc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C]

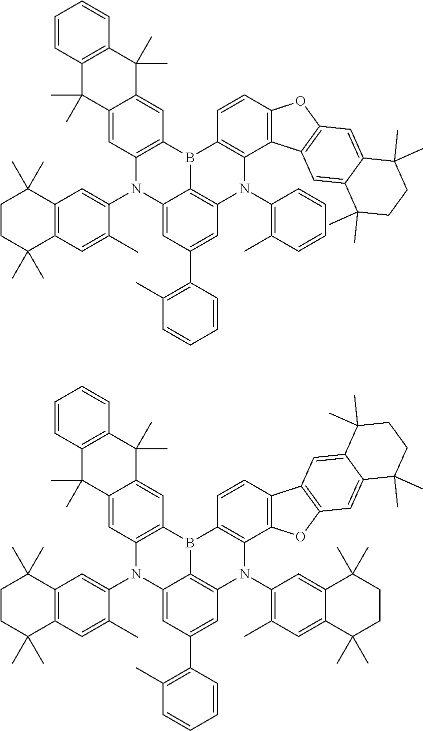 [SMILES: Cc1ccccc1-c1cc2c3c(c1)N(c1ccccc1C)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1oc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

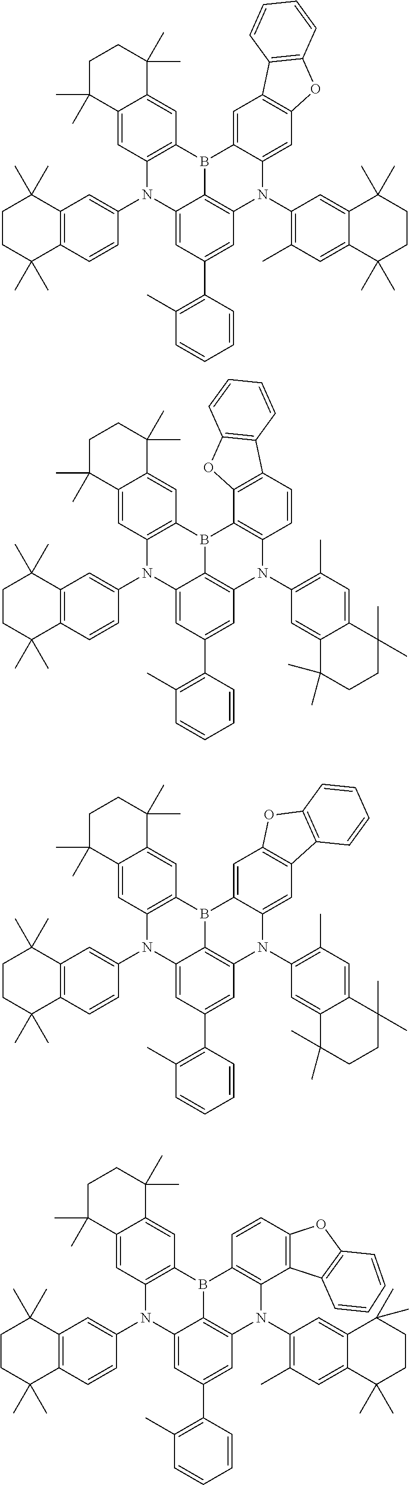

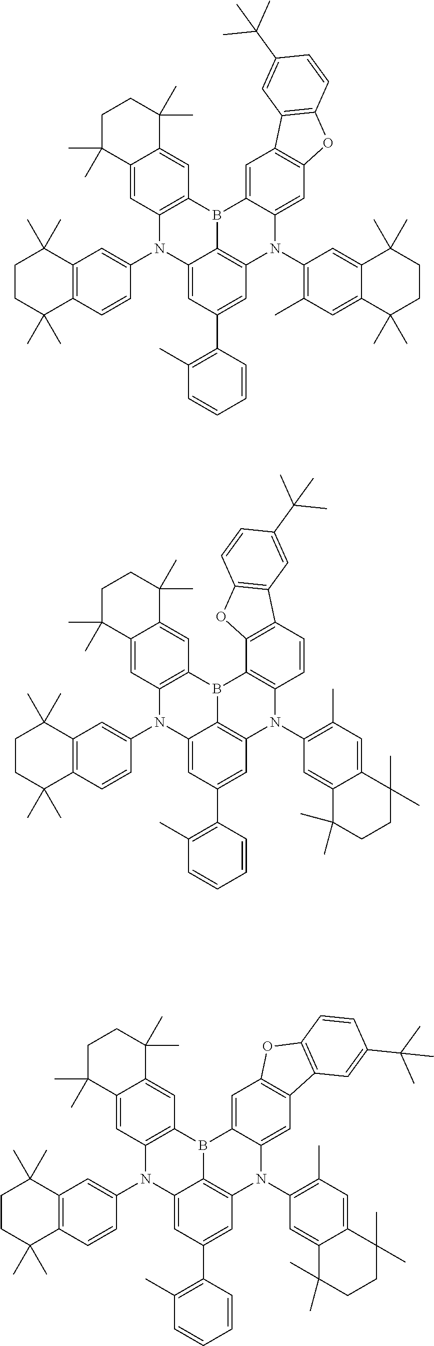 [SMILES: Cc1ccccc1-c1cc2c3c(c1)N(c1cc4c(cc1C)C(C)(C)CCC4(C)C)c1cc4oc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1ccc(C(C)(C)C)cc14]

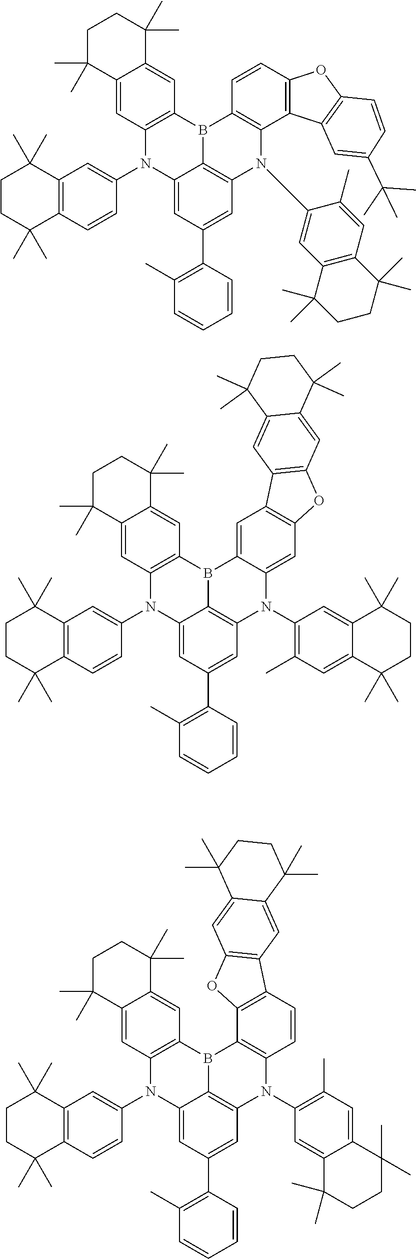

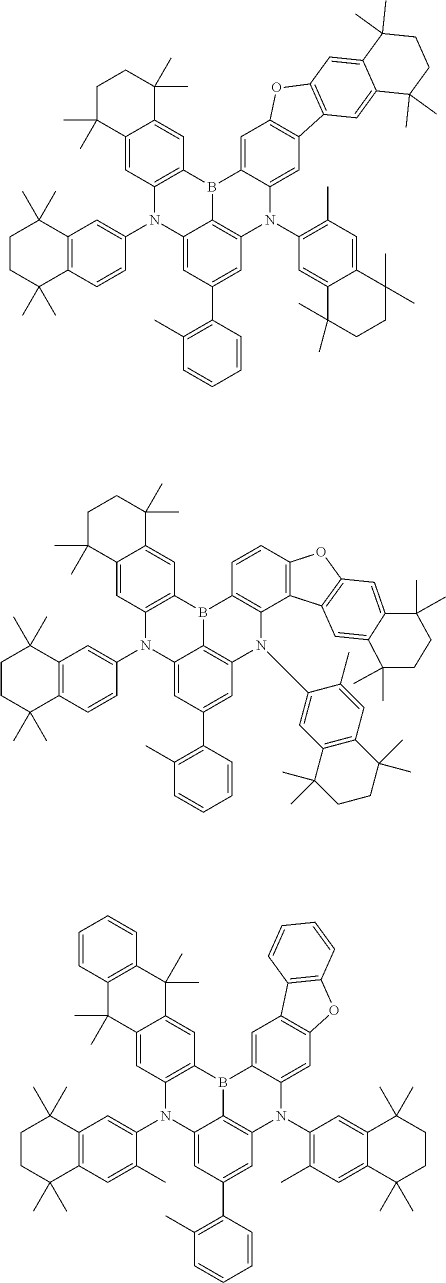 [SMILES: Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1cc2c(cc14)C(C)(C)CCC2(C)C ; Cc1ccccc1-c1cc2c3c(c1)N(c1cc4c(cc1C)C(C)(C)CCC4(C)C)c1c(ccc4oc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4oc5ccccc5c4cc1B3c1cc3c(cc1N2c1cc2c(cc1C)C(C)(C)CCC2(C)C)C(C)(C)c1ccccc1C3(C)C]

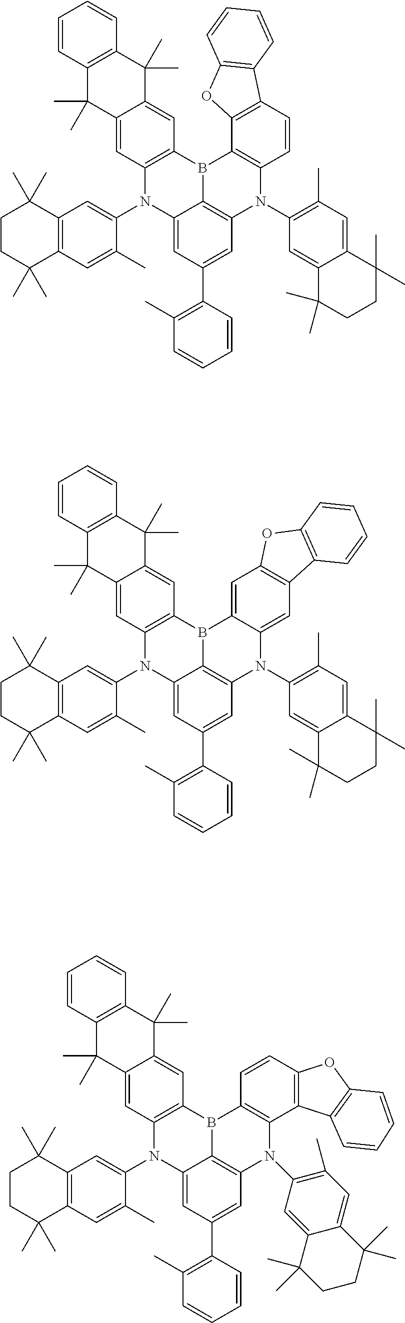 [SMILES: Cc1ccccc1-c1cc2c3c(c1)N(c1cc4c(cc1C)C(C)(C)CCC4(C)C)c1ccc4c(oc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1ccccc14 ; Cc1ccccc1-c1cc2c3c(c1)N(c1cc4c(cc1C)C(C)(C)CCC4(C)C)c1c(ccc4oc5ccccc5c14)B3c1cc3c(cc1N2c1cc2c(cc1C)C(C)(C)CCC2(C)C)C(C)(C)c1ccccc1C3(C)C]

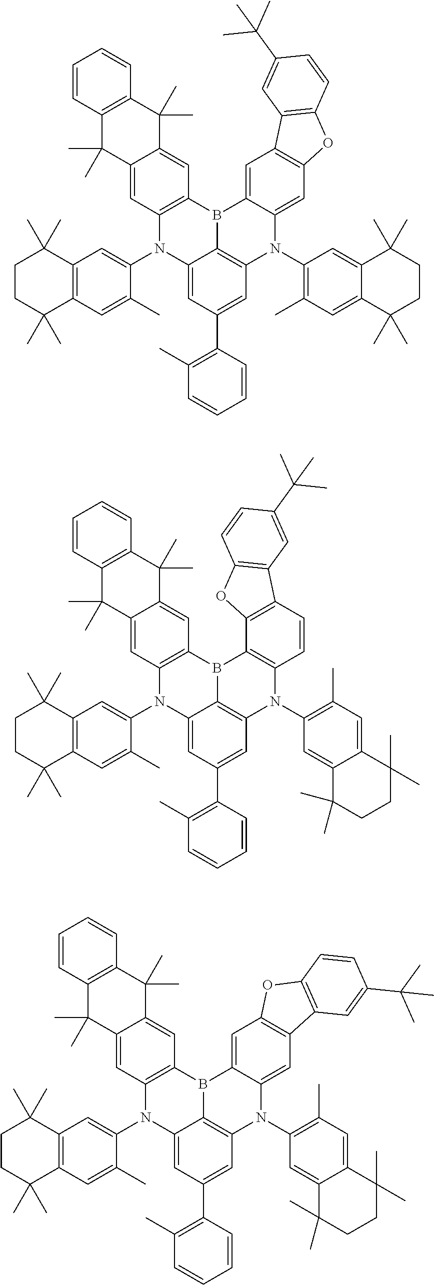 [SMILES: Cc1ccccc1-c1cc2c3c(c1)N(c1cc4c(cc1C)C(C)(C)CCC4(C)C)c1cc4oc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1ccc4c(oc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1ccc(C(C)(C)C)cc14]

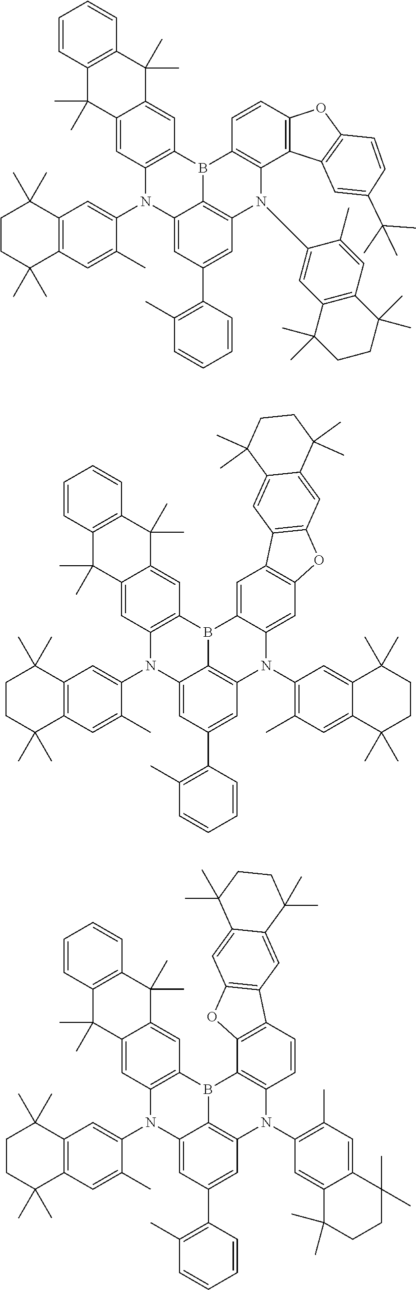

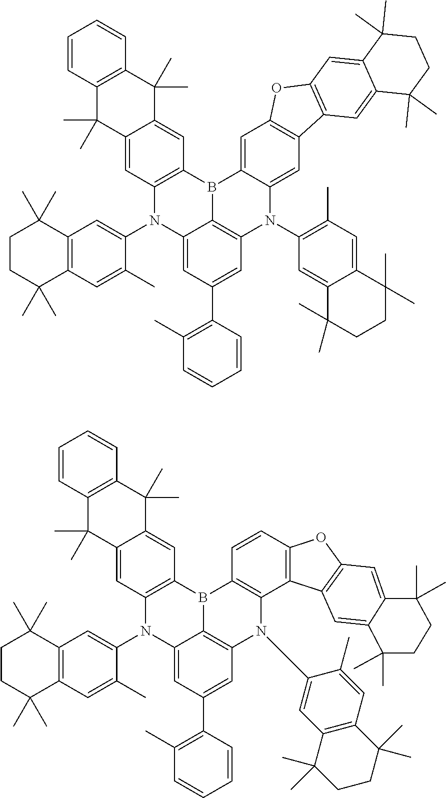 [SMILES: Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)c1ccccc1C3(C)C)oc1cc2c(cc14)C(C)(C)CCC2(C)C ; Cc1ccccc1-c1cc2c3c(c1)N(c1cc4c(cc1C)C(C)(C)CCC4(C)C)c1c(ccc4oc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C]

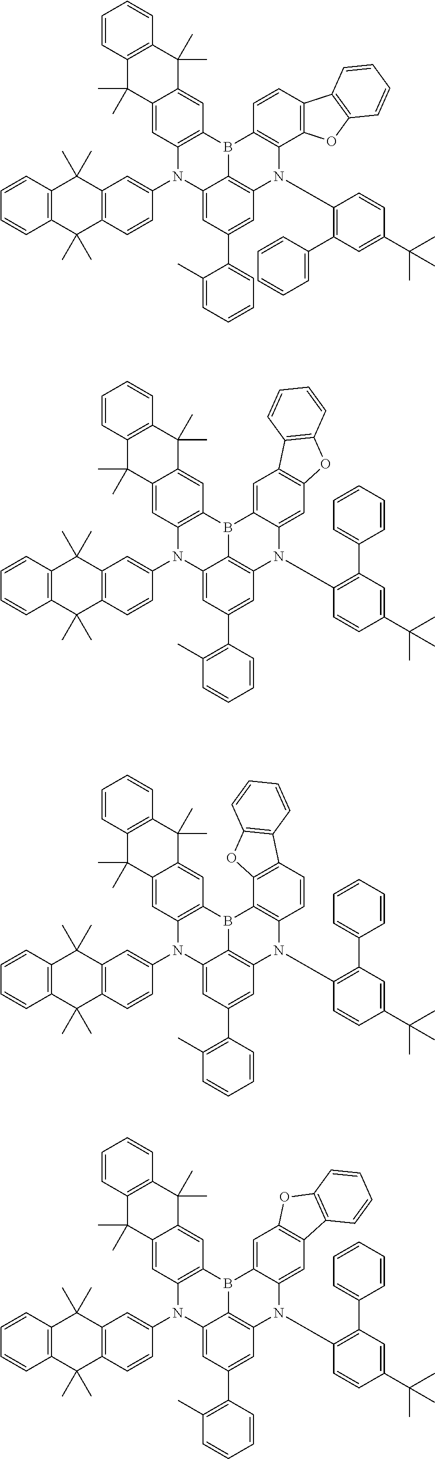

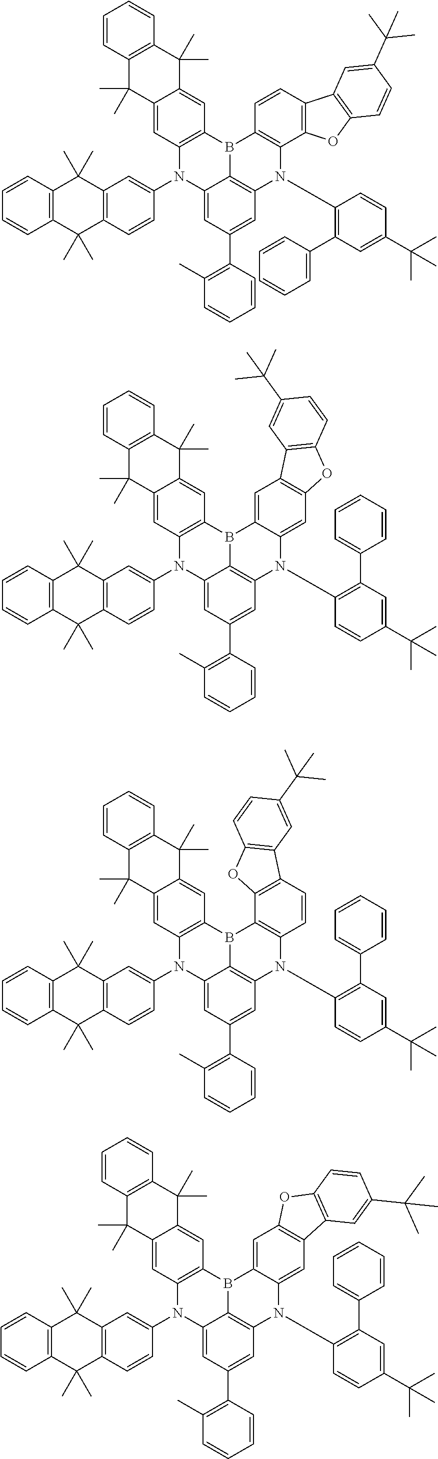

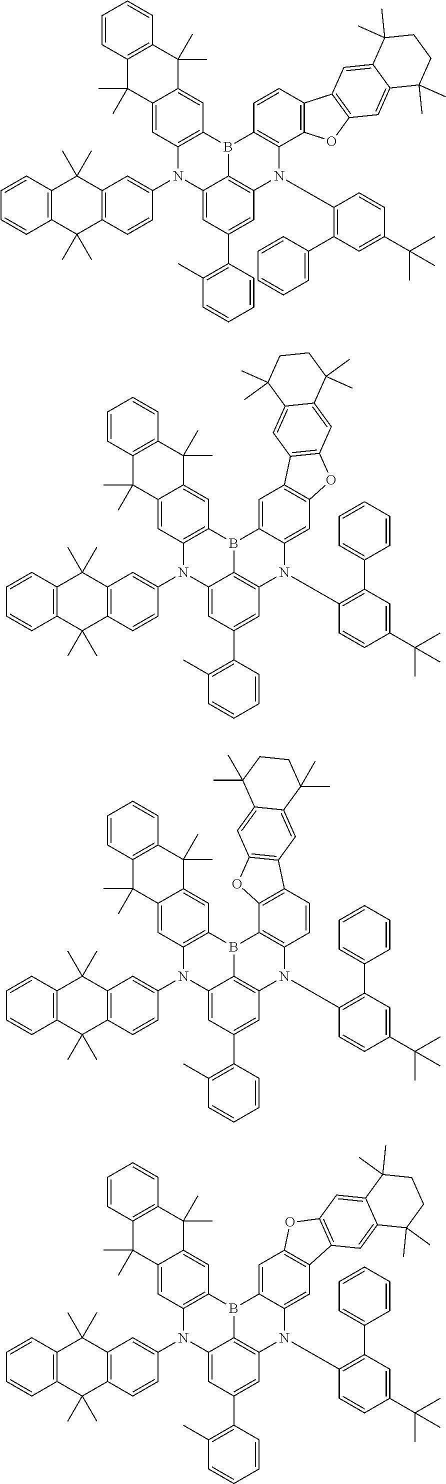

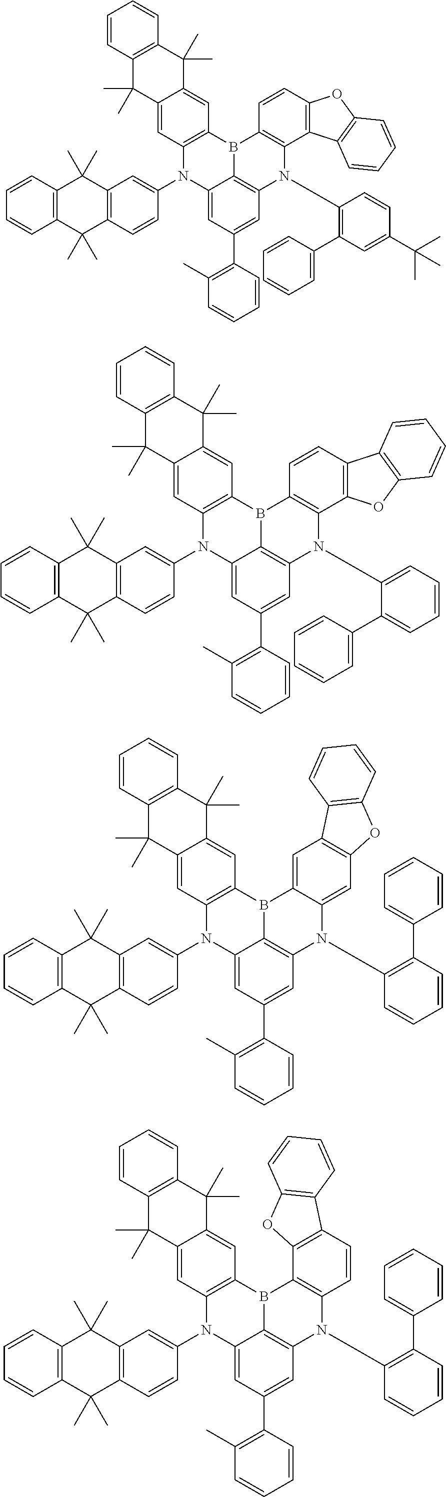

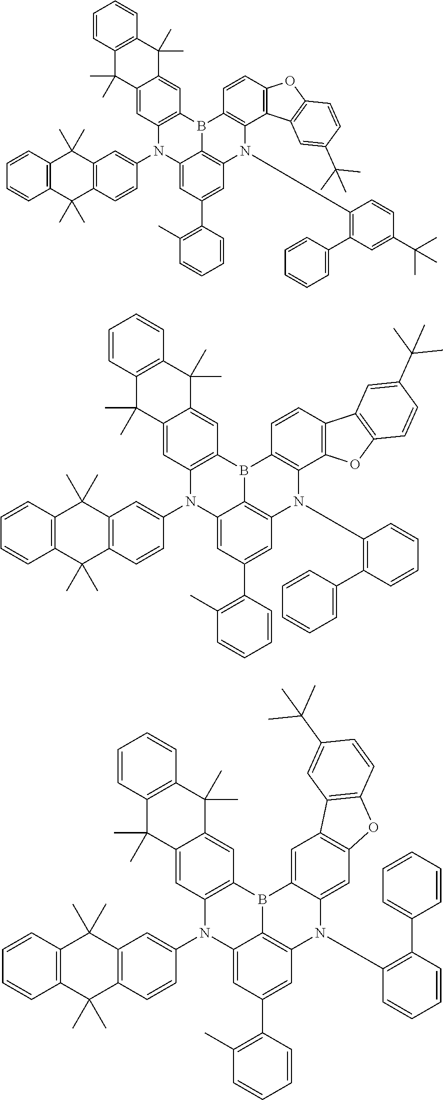 [SMILES: Cc1ccccc1-c1cc2c3c(c1)N(c1ccc(C(C)(C)C)cc1-c1ccccc1)c1c(ccc4oc5ccc(C(C)(C)C)cc5c14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1c(ccc4c1oc1ccc(C(C)(C)C)cc14)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1cc4oc5ccc(C(C)(C)C)cc5c4cc1B3c1cc3c(cc1N2c1ccc2c(c1)C(C)(C)c1ccccc1C2(C)C)C(C)(C)c1ccccc1C3(C)C]

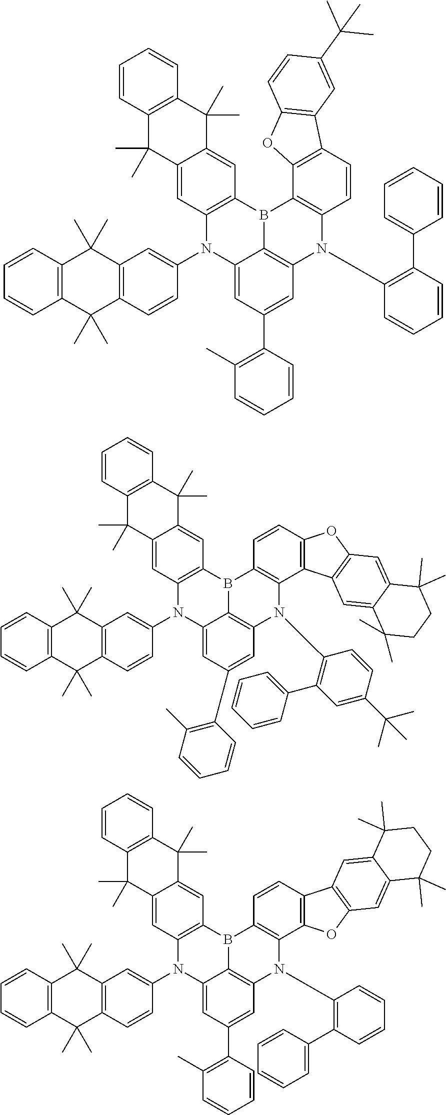 [SMILES: Cc1ccccc1-c1cc2c3c(c1)N(c1ccccc1-c1ccccc1)c1ccc4c(oc5ccc(C(C)(C)C)cc54)c1B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; Cc1ccccc1-c1cc2c3c(c1)N(c1ccccc1-c1ccccc1)c1c(ccc4c1oc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C]

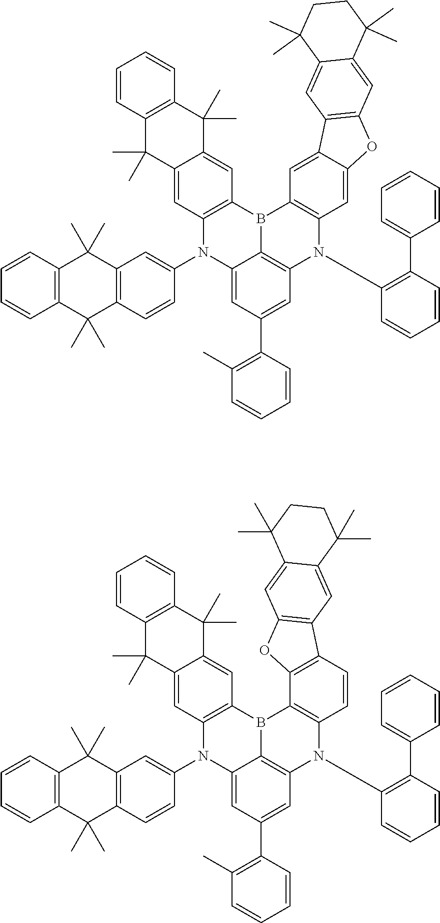 [SMILES: Cc1ccccc1-c1cc2c3c(c1)N(c1ccccc1-c1ccccc1)c1cc4oc5cc6c(cc5c4cc1B3c1cc3c(cc1N2c1ccc2c(c1)C(C)(C)c1ccccc1C2(C)C)C(C)(C)c1ccccc1C3(C)C)C(C)(C)CCC6(C)C ; Cc1ccccc1-c1cc2c3c(c1)N(c1ccccc1-c1ccccc1)c1ccc4c(oc5cc6c(cc54)C(C)(C)CCC6(C)C)c1B3c1cc3c(cc1N2c1ccc2c(c1)C(C)(C)c1ccccc1C2(C)C)C(C)(C)c1ccccc1C3(C)C]

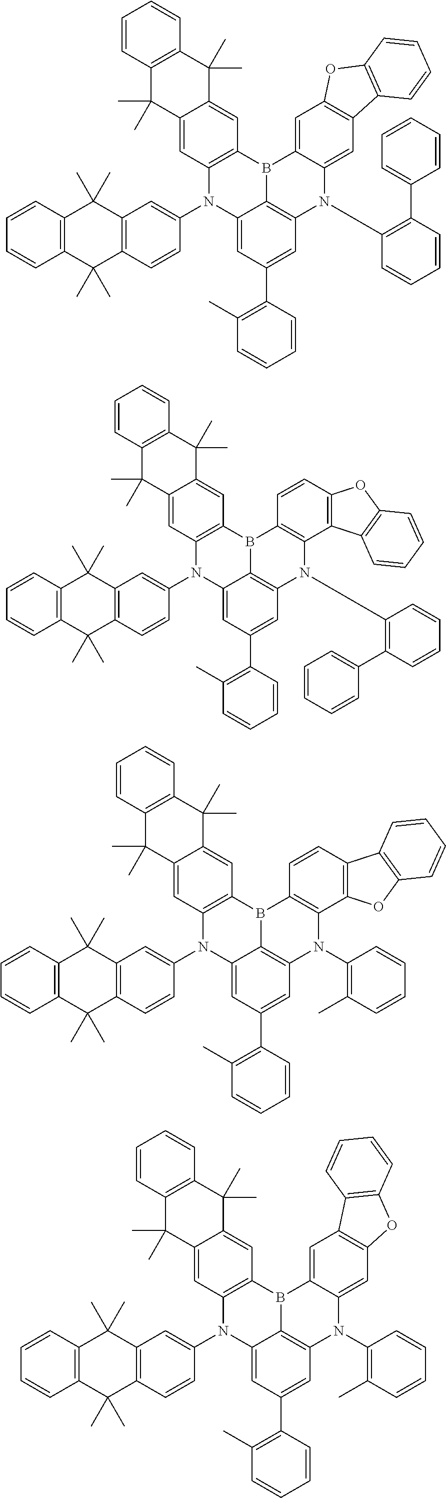

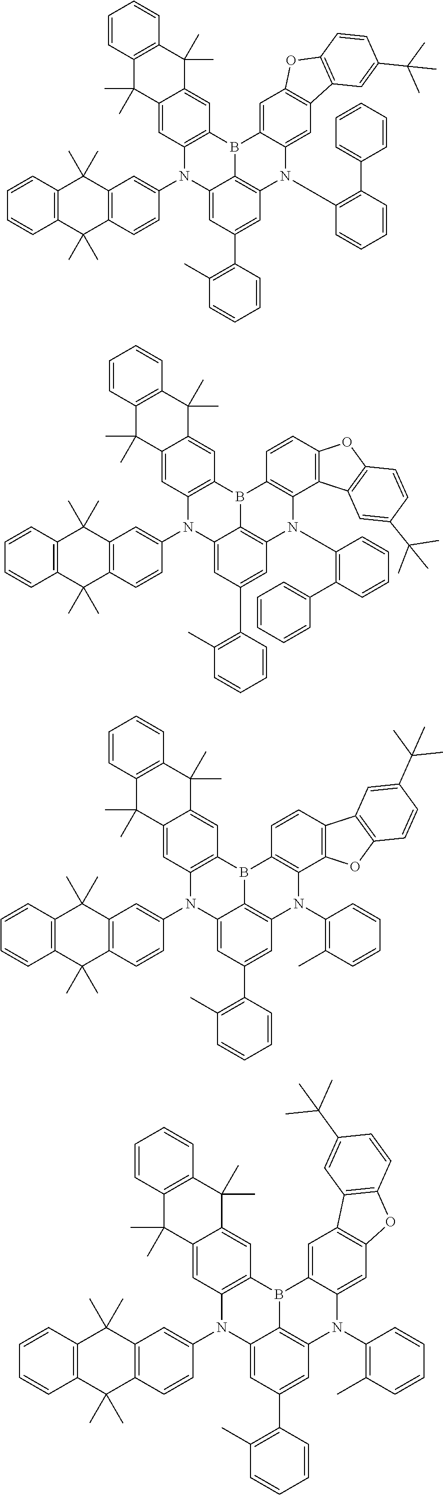

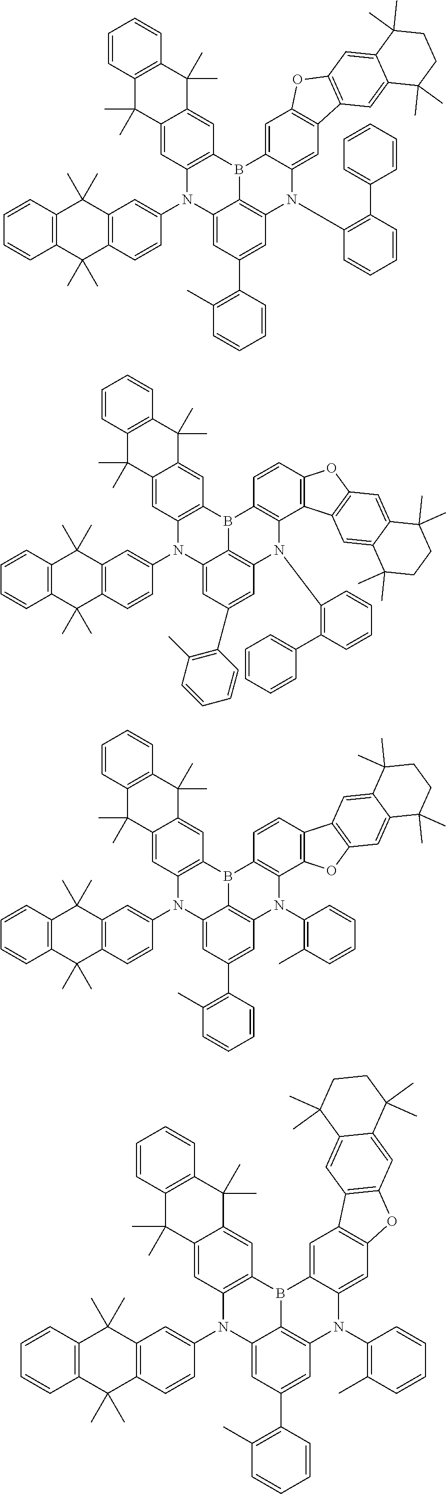

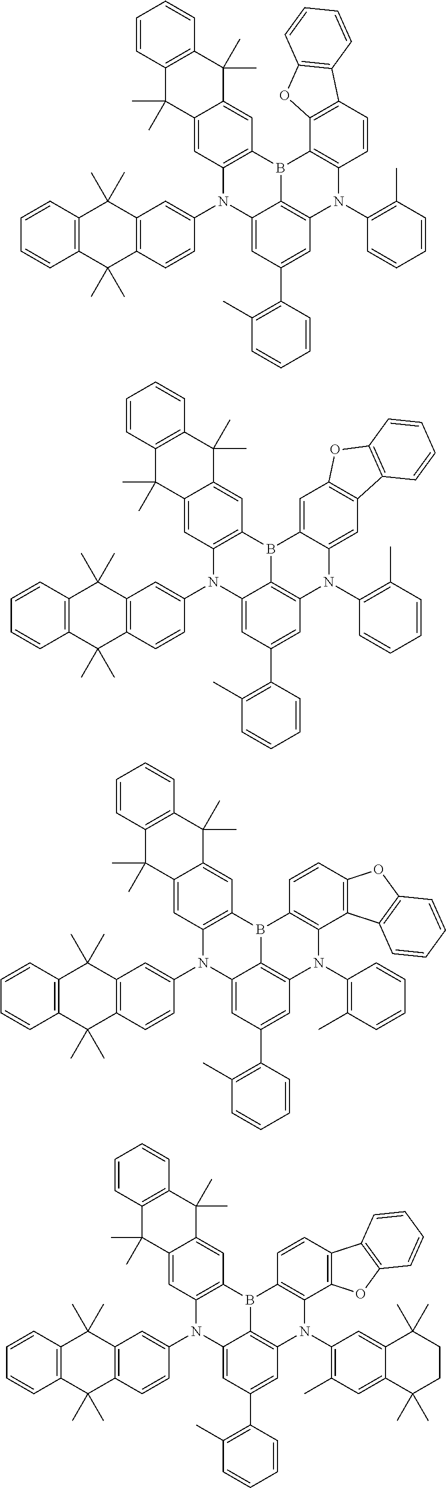

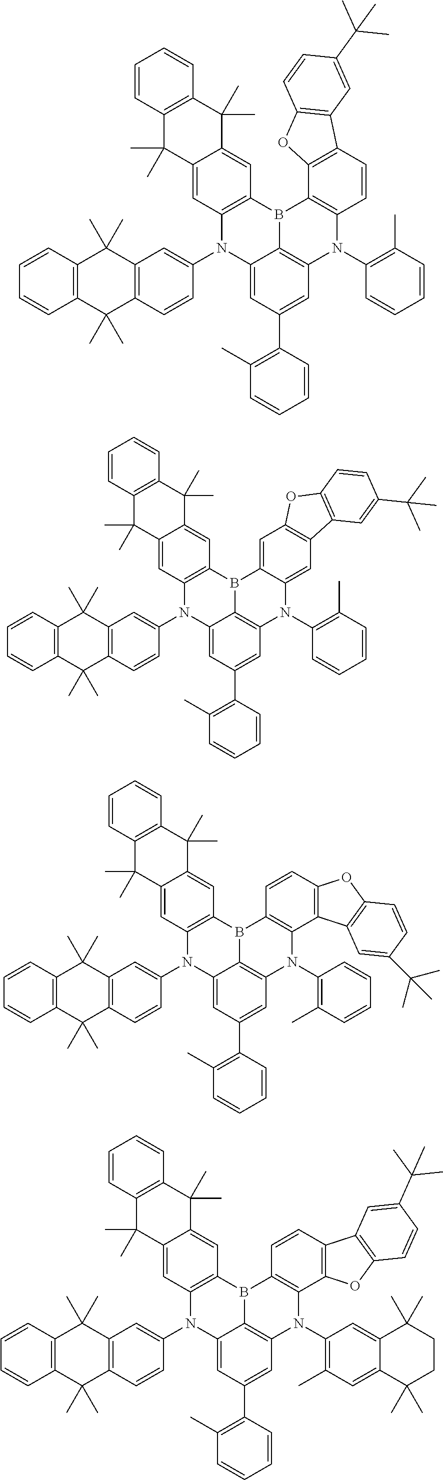

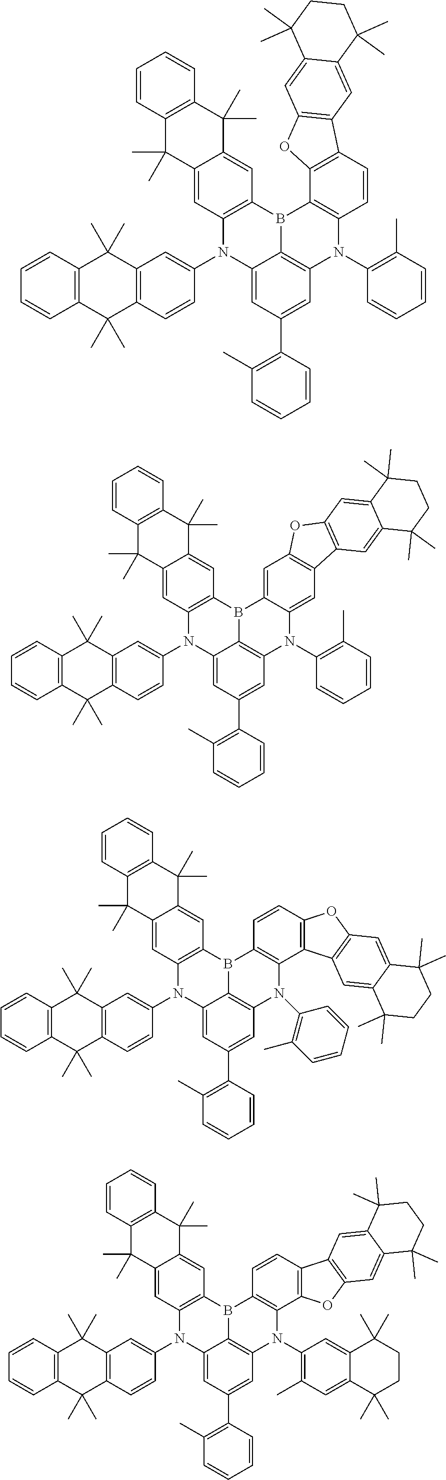

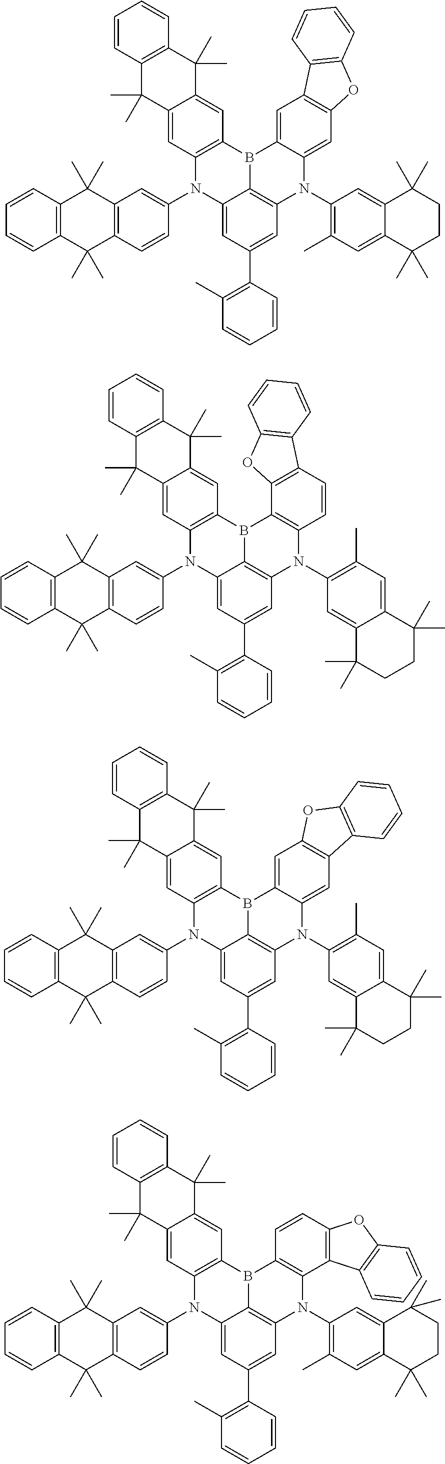

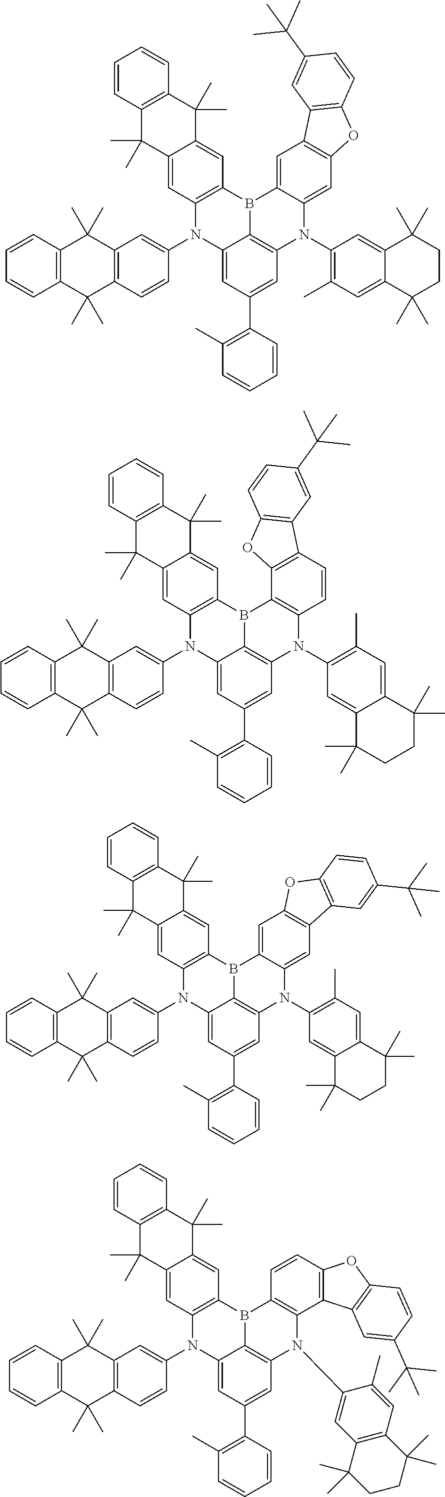

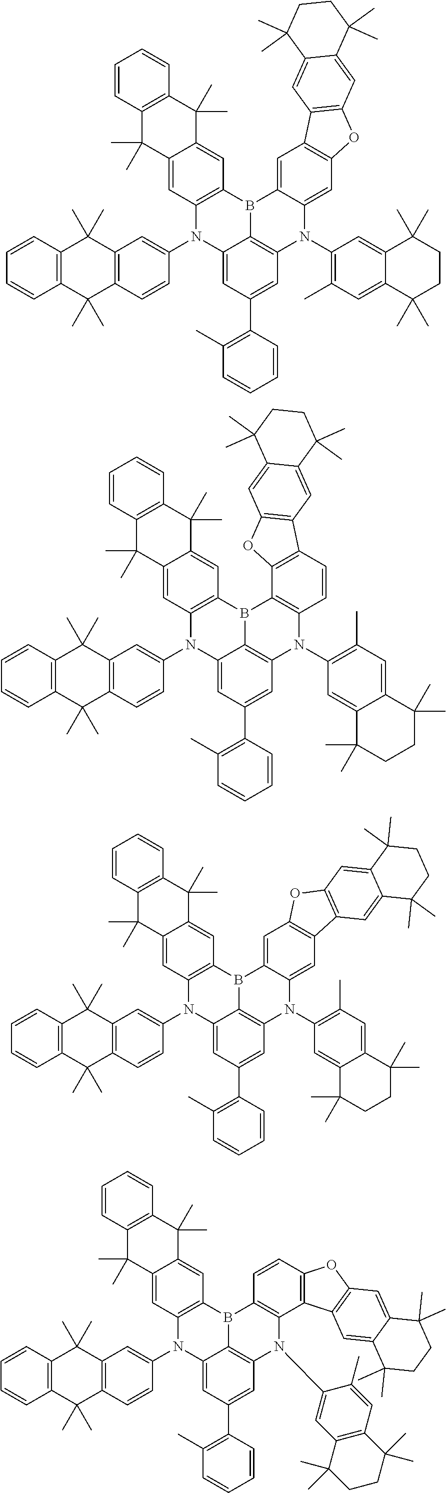

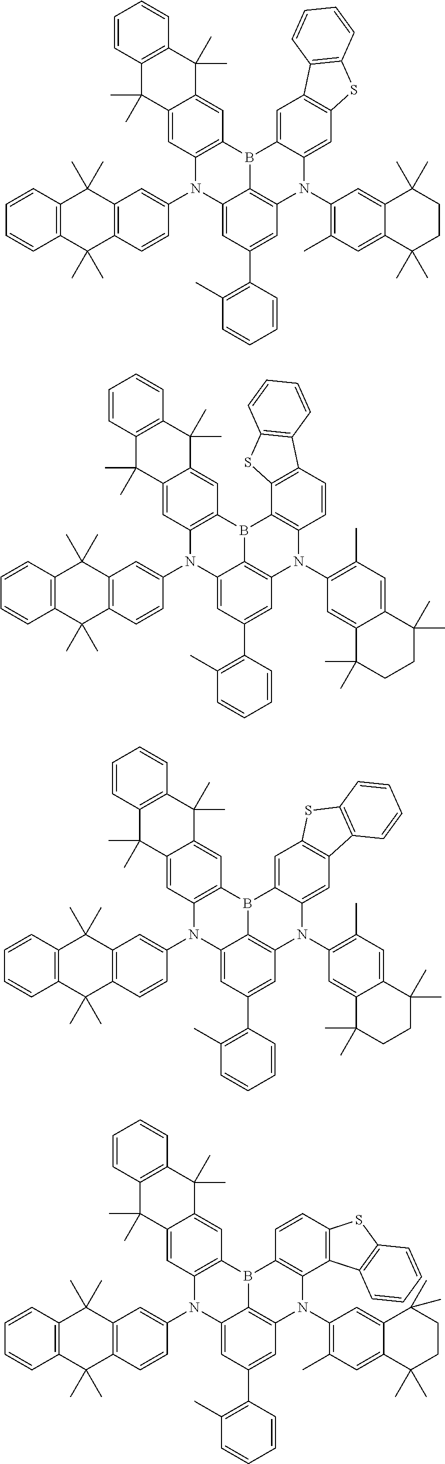

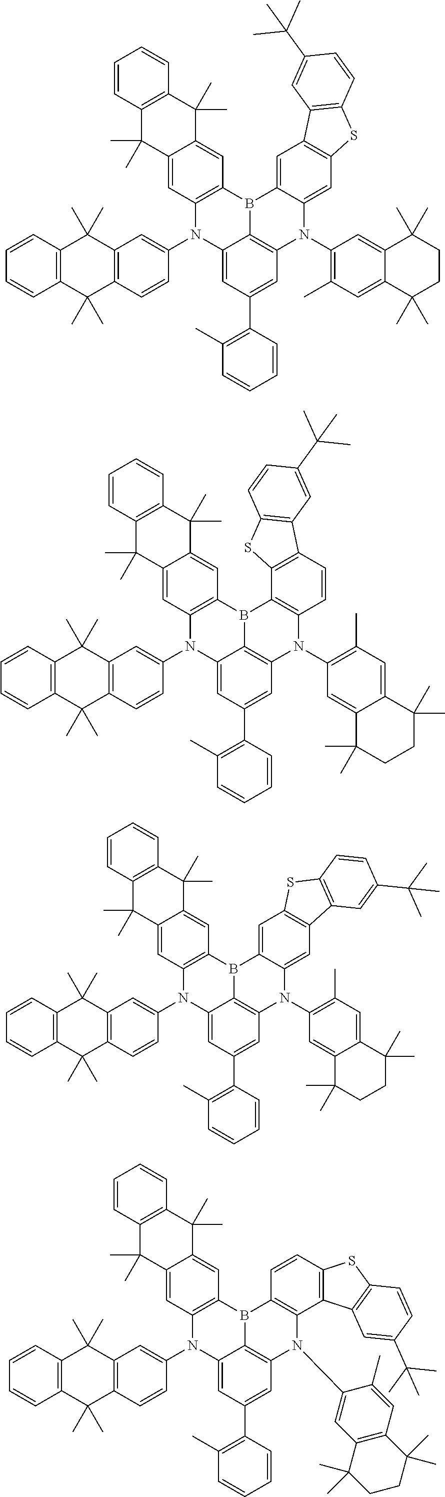

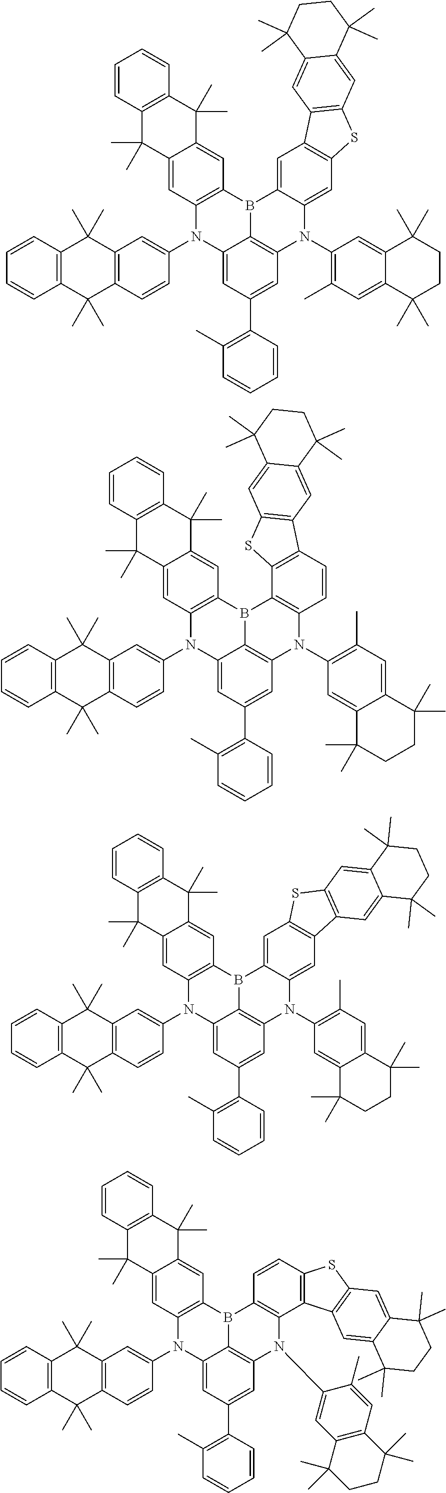

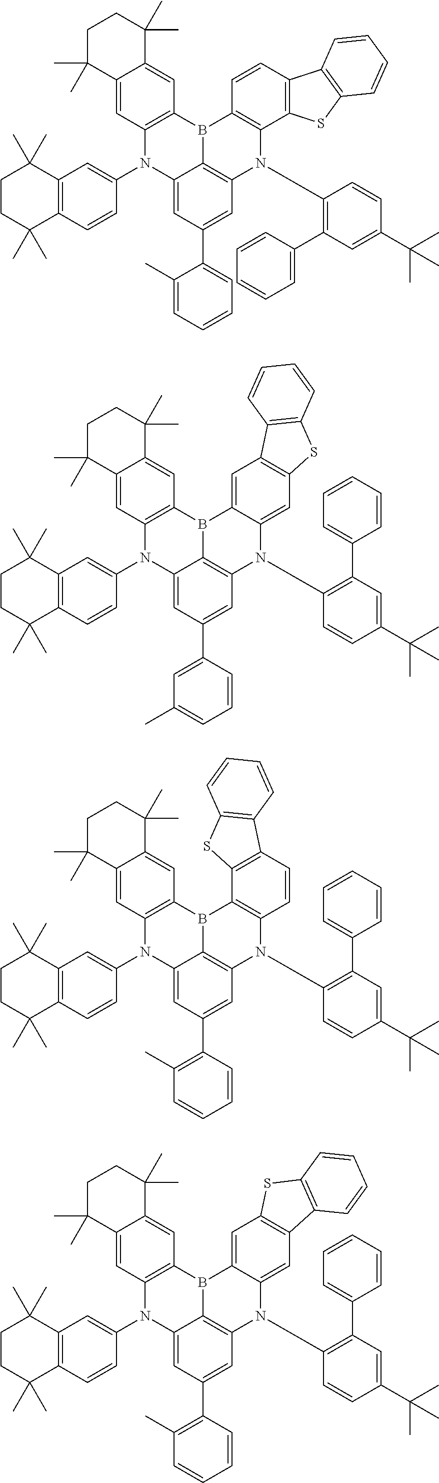

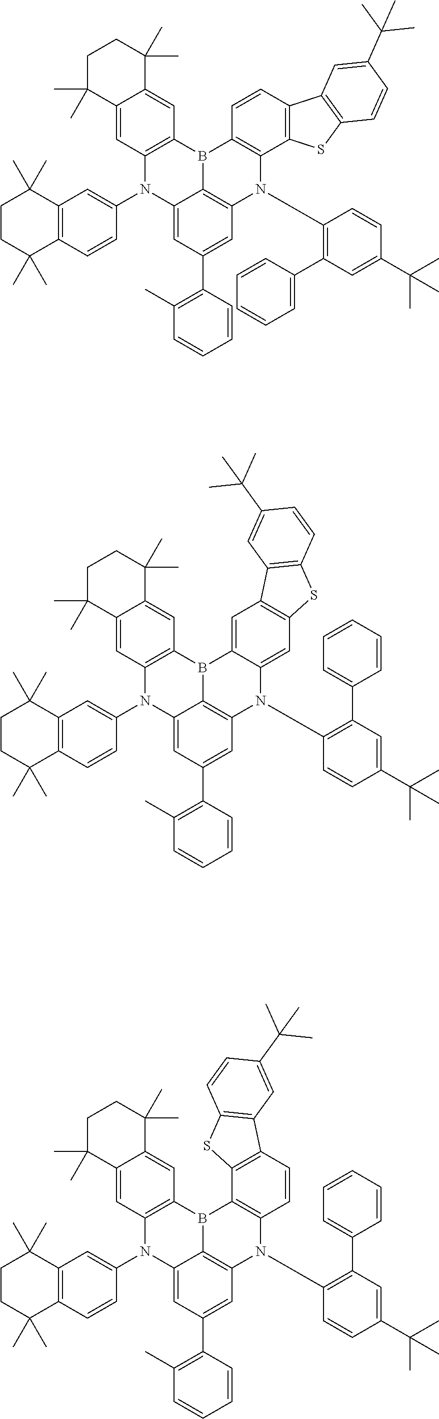 [SMILES: Cc1ccccc1-c1cc2c3c(c1)N(c1ccc(C(C)(C)C)cc1-c1ccccc1)c1c(ccc4c1sc1ccc(C(C)(C)C)cc14)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4sc5ccc(C(C)(C)C)cc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1ccc4c(sc5ccc(C(C)(C)C)cc54)c1B3c1cc3c(cc1N2c1ccc2c(c1)C(C)(C)CCC2(C)C)C(C)(C)CCC3(C)C]

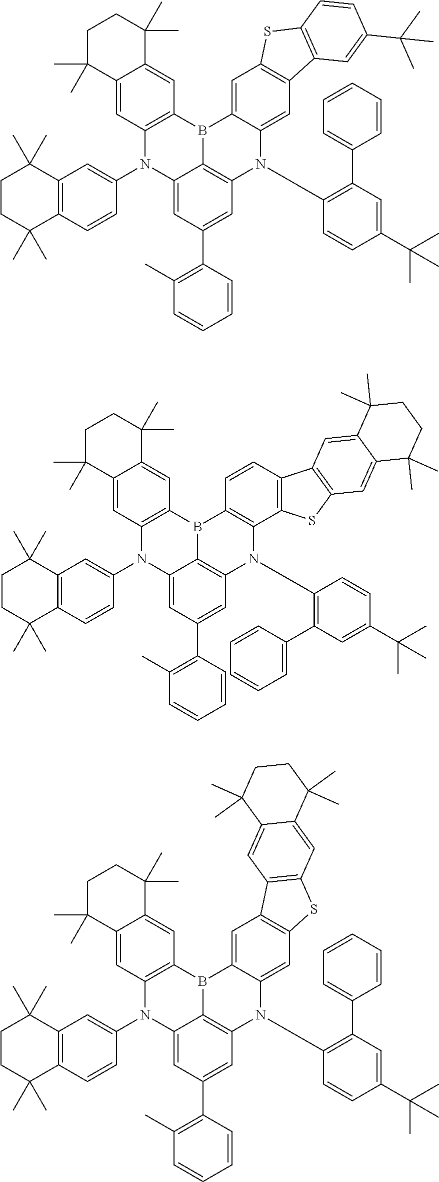 [SMILES: Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1ccc(C(C)(C)C)cc14 ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4sc5cc6c(cc5c4cc1B3c1cc3c(cc1N2c1ccc2c(c1)C(C)(C)CCC2(C)C)C(C)(C)CCC3(C)C)C(C)(C)CCC6(C)C]

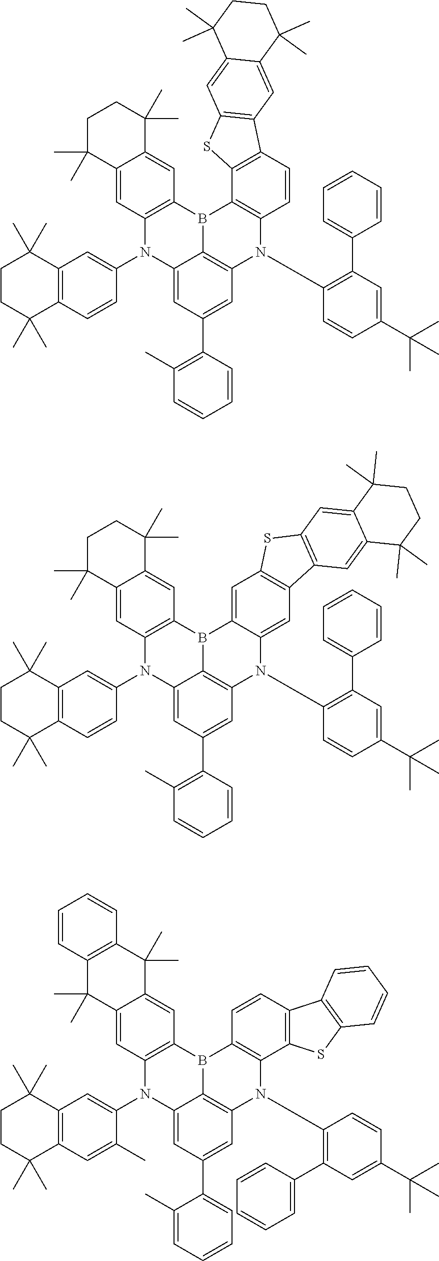 [SMILES: Cc1ccccc1-c1cc2c3c(c1)N(c1ccc(C(C)(C)C)cc1-c1ccccc1)c1ccc4c(sc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1cc2c(cc14)C(C)(C)CCC2(C)C ; Cc1ccccc1-c1cc2c3c(c1)N(c1ccc(C(C)(C)C)cc1-c1ccccc1)c1c(ccc4c1sc1ccccc14)B3c1cc3c(cc1N2c1cc2c(cc1C)C(C)(C)CCC2(C)C)C(C)(C)c1ccccc1C3(C)C]

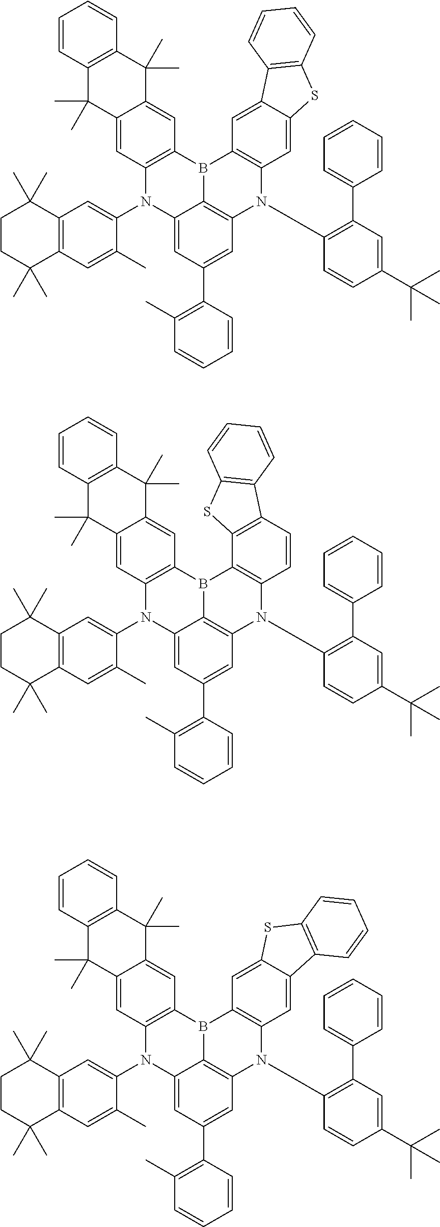 [SMILES: Cc1ccccc1-c1cc2c3c(c1)N(c1ccc(C(C)(C)C)cc1-c1ccccc1)c1cc4sc5ccccc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1ccc4c(sc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1ccccc14]

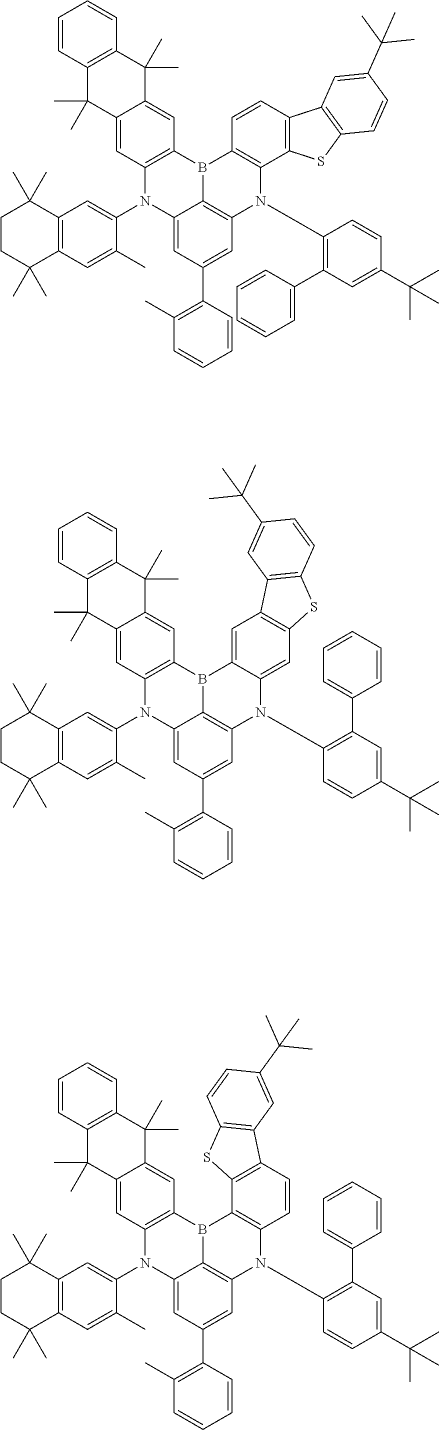 [SMILES: Cc1ccccc1-c1cc2c3c(c1)N(c1ccc(C(C)(C)C)cc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4sc5ccc(C(C)(C)C)cc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C]

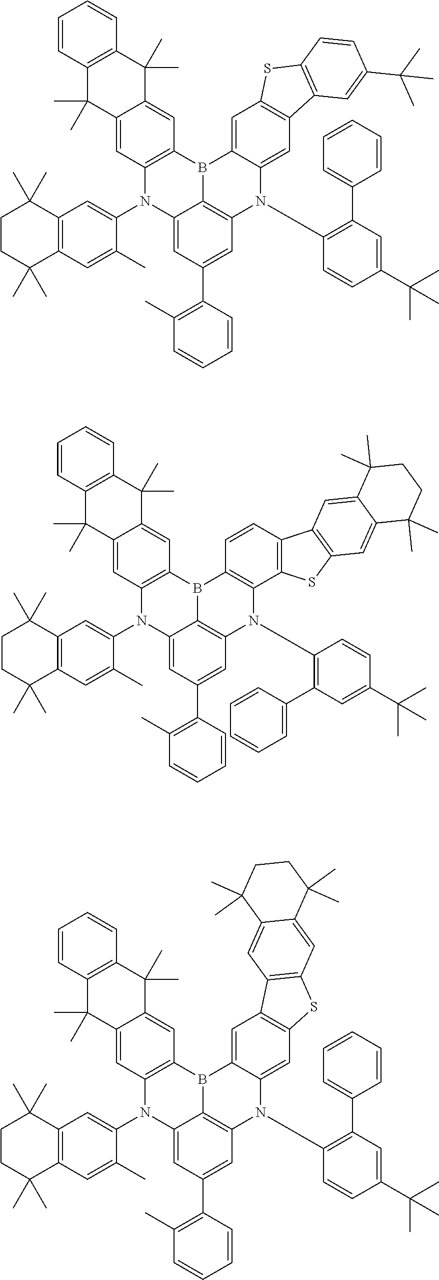 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1ccc(C(C)(C)C)cc14 ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4sc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C]

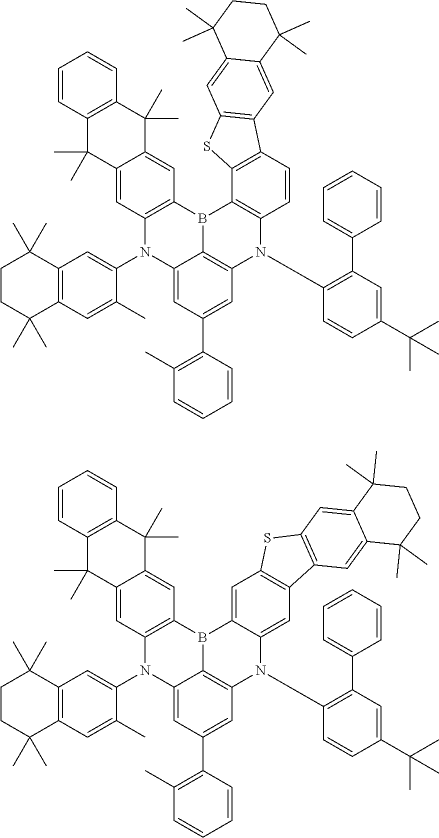 [SMILES: Cc1ccccc1-c1cc2c3c(c1)N(c1ccc(C(C)(C)C)cc1-c1ccccc1)c1ccc4c(sc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)c1ccccc1C3(C)C)sc1cc2c(cc14)C(C)(C)CCC2(C)C]

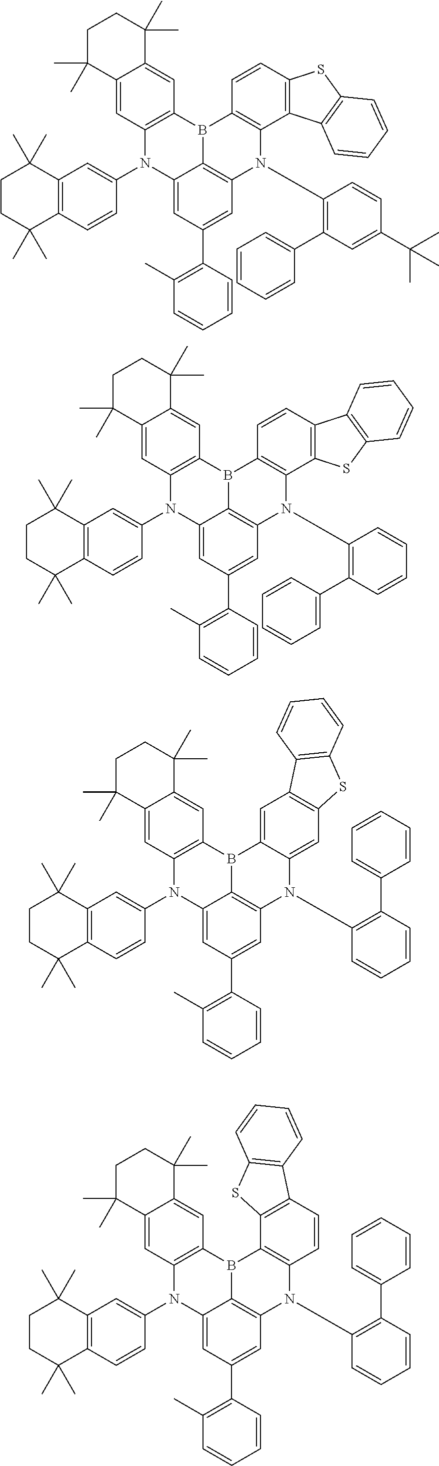

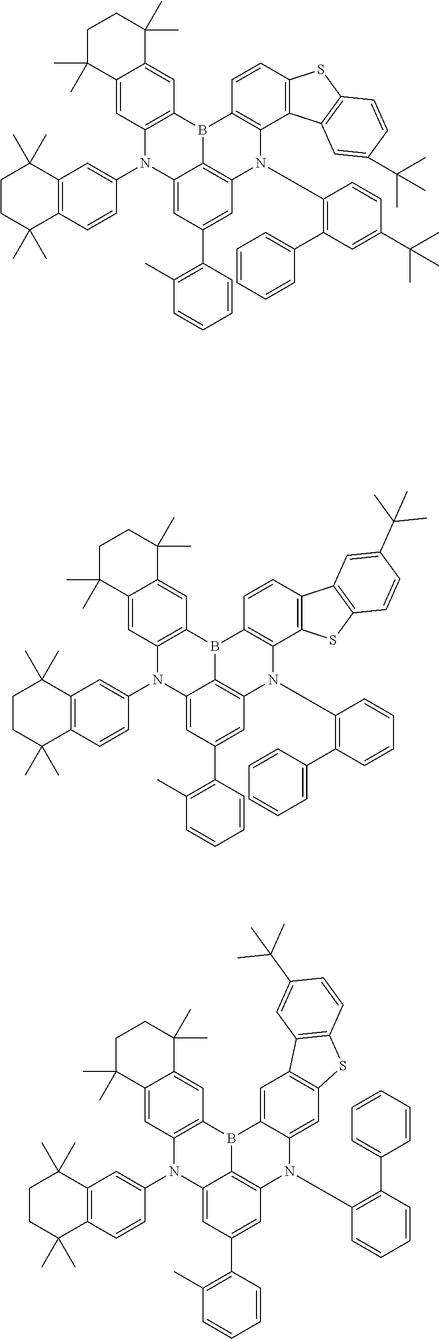 [SMILES: Cc1ccccc1-c1cc2c3c(c1)N(c1ccc(C(C)(C)C)cc1-c1ccccc1)c1c(ccc4sc5ccc(C(C)(C)C)cc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1sc1ccc(C(C)(C)C)cc14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1cc4sc5ccc(C(C)(C)C)cc5c4cc1B3c1cc3c(cc1N2c1ccc2c(c1)C(C)(C)CCC2(C)C)C(C)(C)CCC3(C)C]

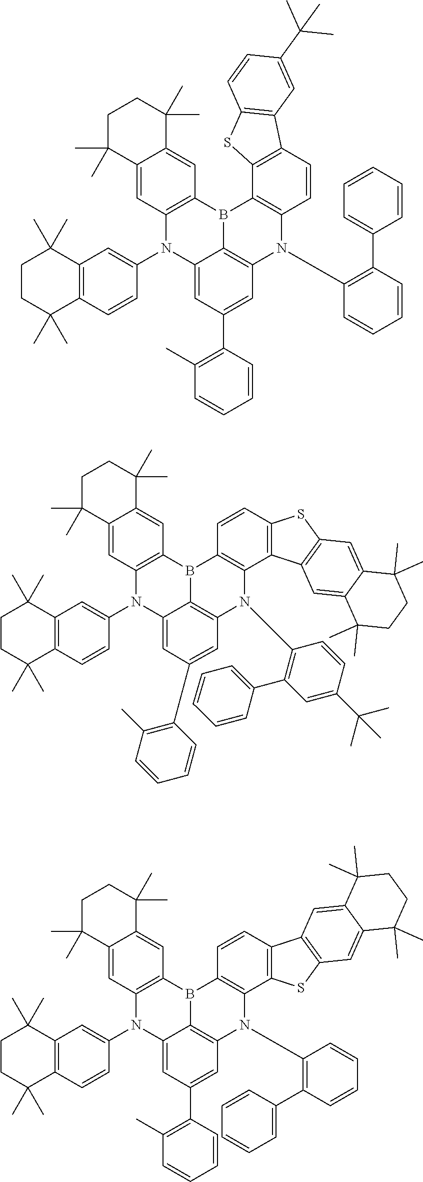 [SMILES: Cc1ccccc1-c1cc2c3c(c1)N(c1ccccc1-c1ccccc1)c1ccc4c(sc5ccc(C(C)(C)C)cc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1-c1ccccc1)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C]

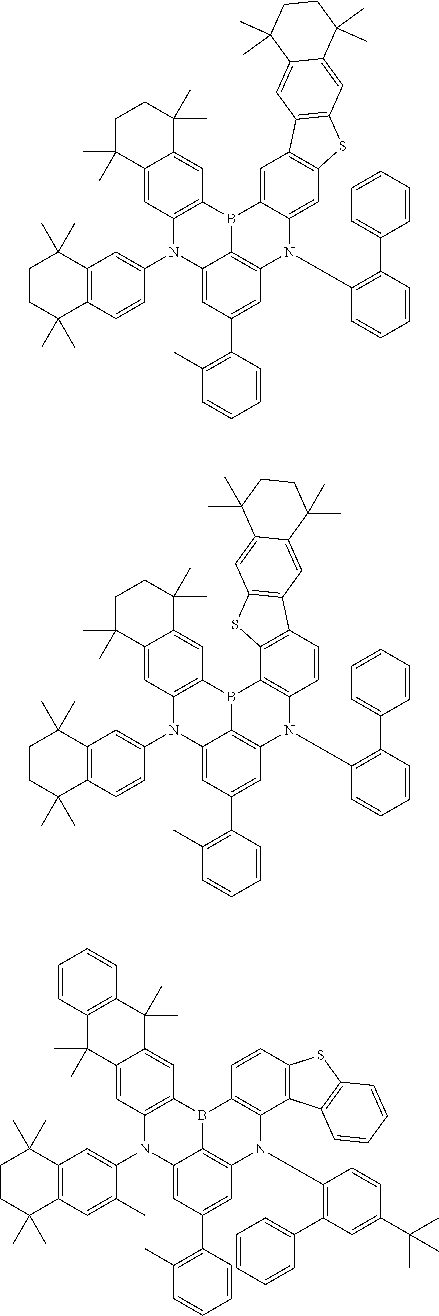 [SMILES: Cc1ccccc1-c1cc2c3c(c1)N(c1ccccc1-c1ccccc1)c1cc4sc5cc6c(cc5c4cc1B3c1cc3c(cc1N2c1ccc2c(c1)C(C)(C)CCC2(C)C)C(C)(C)CCC3(C)C)C(C)(C)CCC6(C)C ; Cc1ccccc1-c1cc2c3c(c1)N(c1ccccc1-c1ccccc1)c1ccc4c(sc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C]

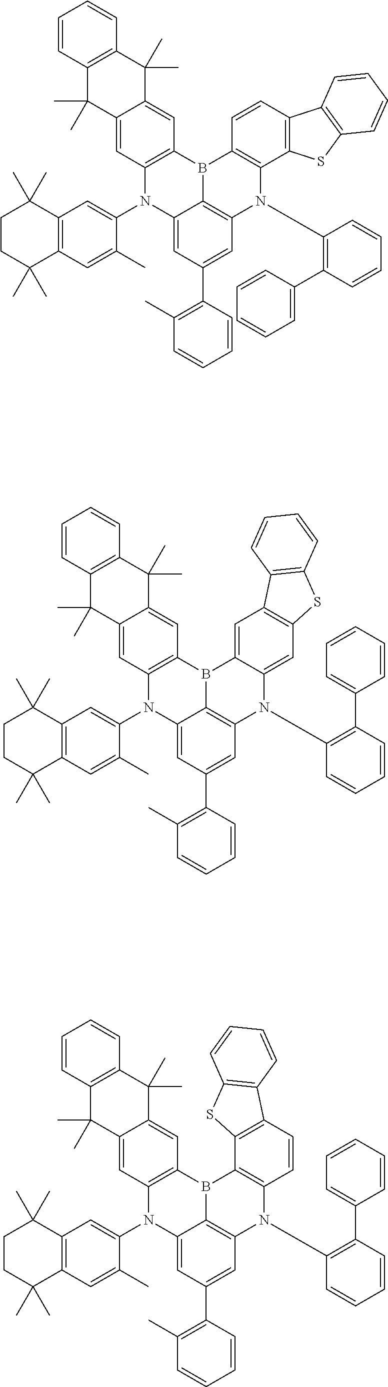 [SMILES: Cc1ccccc1-c1cc2c3c(c1)N(c1ccccc1-c1ccccc1)c1c(ccc4c1sc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4sc5ccccc5c4cc1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1ccc4c(sc5ccccc54)c1B3c1cc3c(cc1N2c1cc2c(cc1C)C(C)(C)CCC2(C)C)C(C)(C)c1ccccc1C3(C)C]

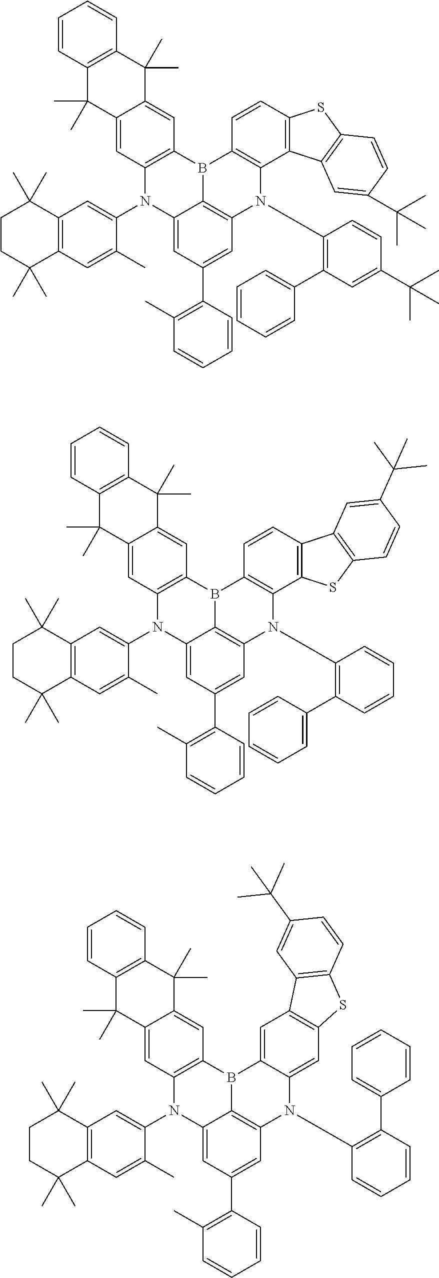 [SMILES: Cc1ccccc1-c1cc2c3c(c1)N(c1ccc(C(C)(C)C)cc1-c1ccccc1)c1c(ccc4sc5ccc(C(C)(C)C)cc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1cc4sc5ccc(C(C)(C)C)cc5c4cc1B3c1cc3c(cc1N2c1cc2c(cc1C)C(C)(C)CCC2(C)C)C(C)(C)c1ccccc1C3(C)C]

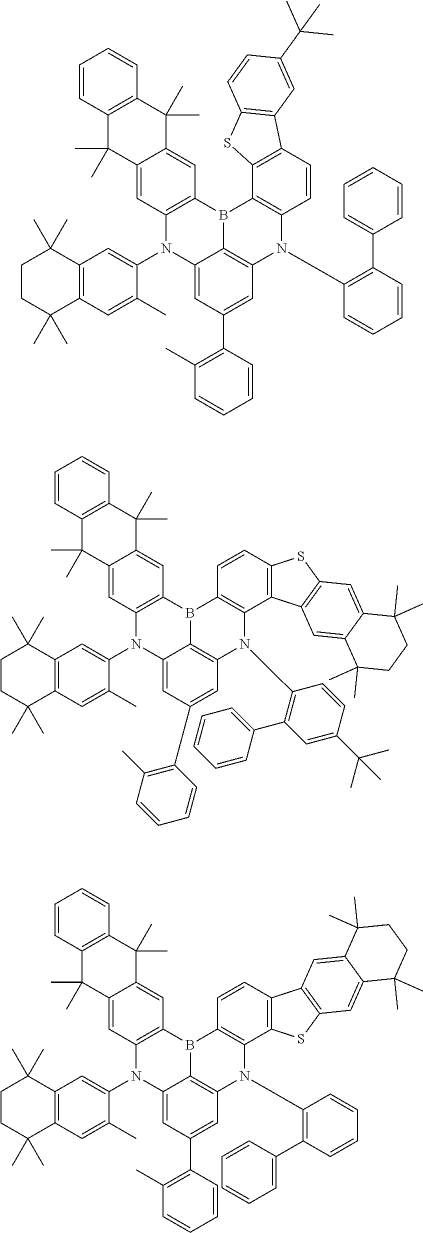 [SMILES: Cc1ccccc1-c1cc2c3c(c1)N(c1ccccc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccc(C(C)(C)C)cc1-c1ccccc1)c1c(ccc4sc5cc6c(cc5c14)C(C)(C)CCC6(C)C)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)c1ccccc1C3(C)C]

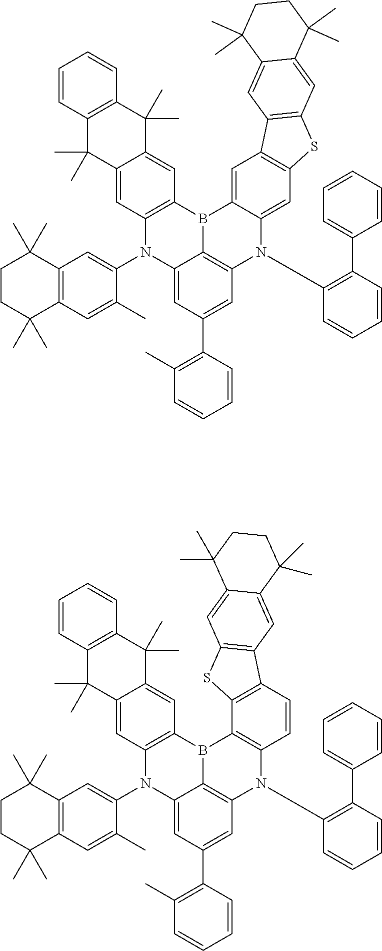 [SMILES: Cc1ccccc1-c1cc2c3c(c1)N(c1ccccc1-c1ccccc1)c1cc4sc5cc6c(cc5c4cc1B3c1cc3c(cc1N2c1cc2c(cc1C)C(C)(C)CCC2(C)C)C(C)(C)c1ccccc1C3(C)C)C(C)(C)CCC6(C)C ; Cc1ccccc1-c1cc2c3c(c1)N(c1ccccc1-c1ccccc1)c1ccc4c(sc5cc6c(cc54)C(C)(C)CCC6(C)C)c1B3c1cc3c(cc1N2c1cc2c(cc1C)C(C)(C)CCC2(C)C)C(C)(C)c1ccccc1C3(C)C]

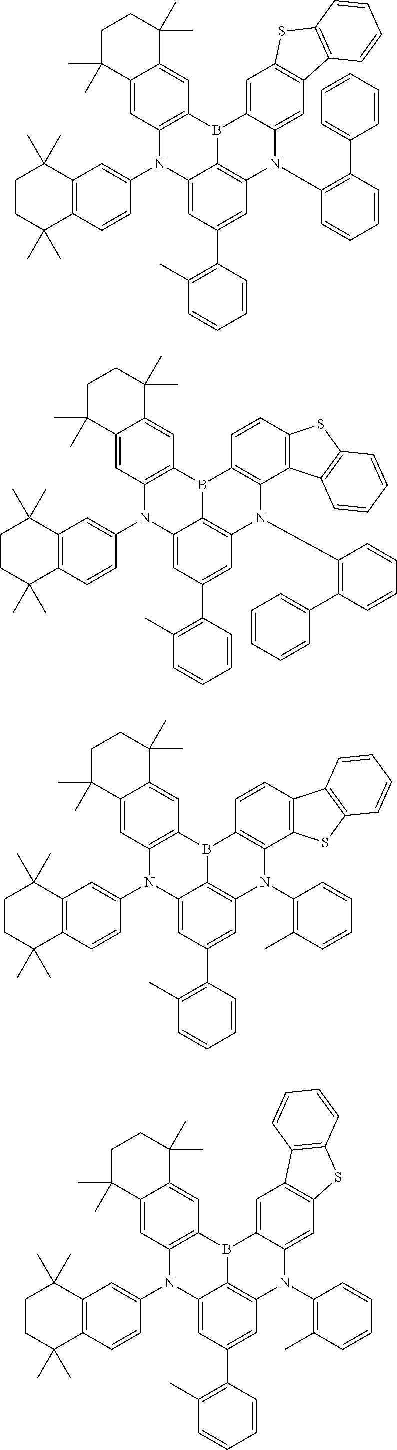 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)sc1ccccc14 ; Cc1ccccc1-c1cc2c3c(c1)N(c1ccccc1-c1ccccc1)c1c(ccc4sc5ccccc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1c(ccc4c1sc1ccccc14)B3c1cc3c(cc1N2c1ccc2c(c1)C(C)(C)CCC2(C)C)C(C)(C)CCC3(C)C ; Cc1ccccc1-c1cc2c3c(c1)N(c1ccccc1C)c1cc4sc5ccccc5c4cc1B3c1cc3c(cc1N2c1ccc2c(c1)C(C)(C)CCC2(C)C)C(C)(C)CCC3(C)C]

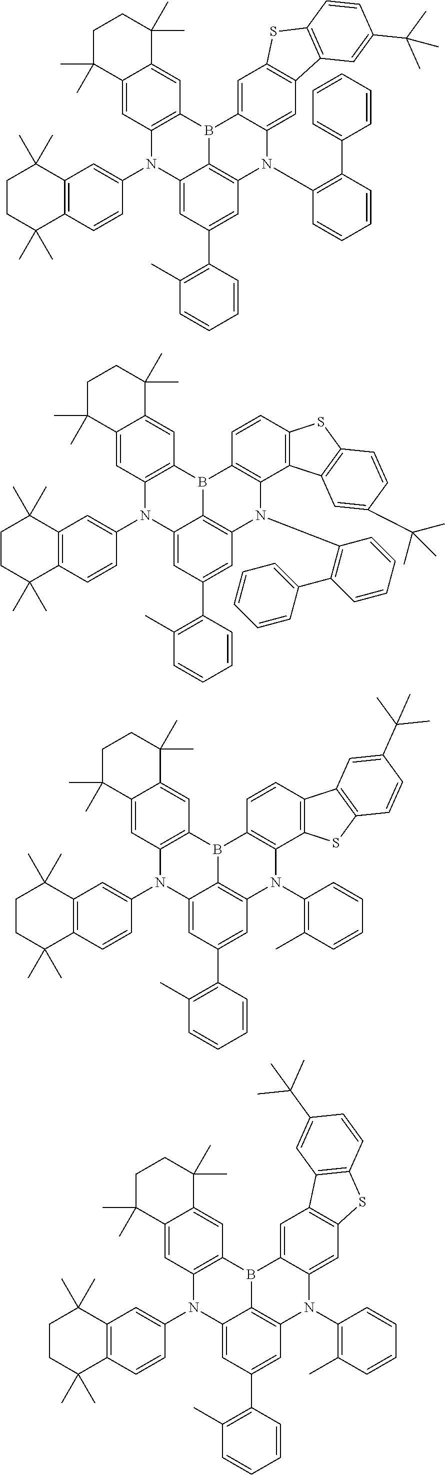

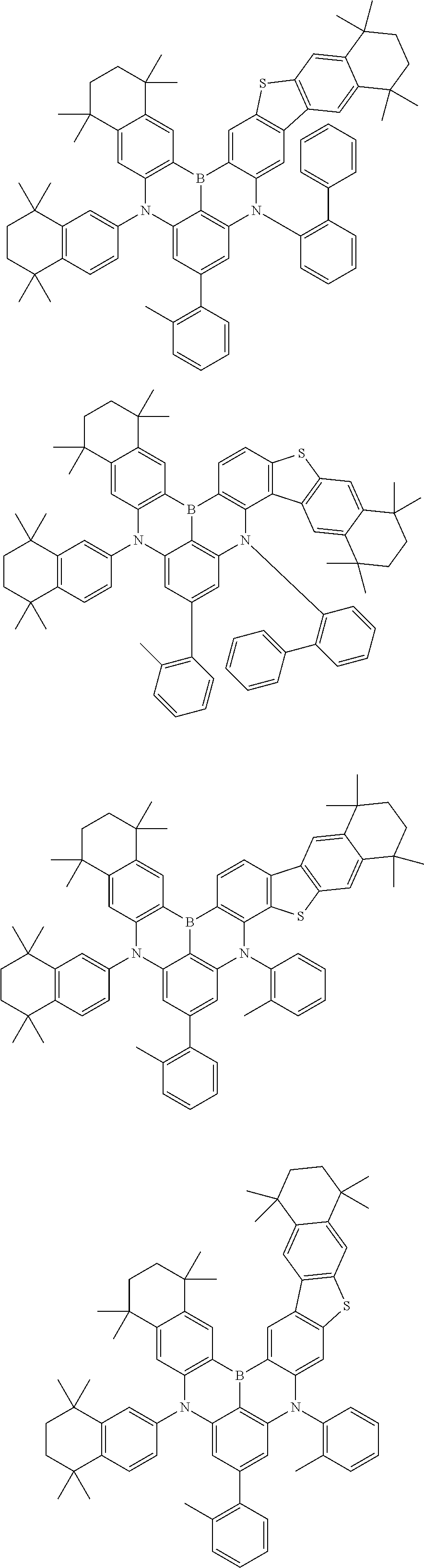

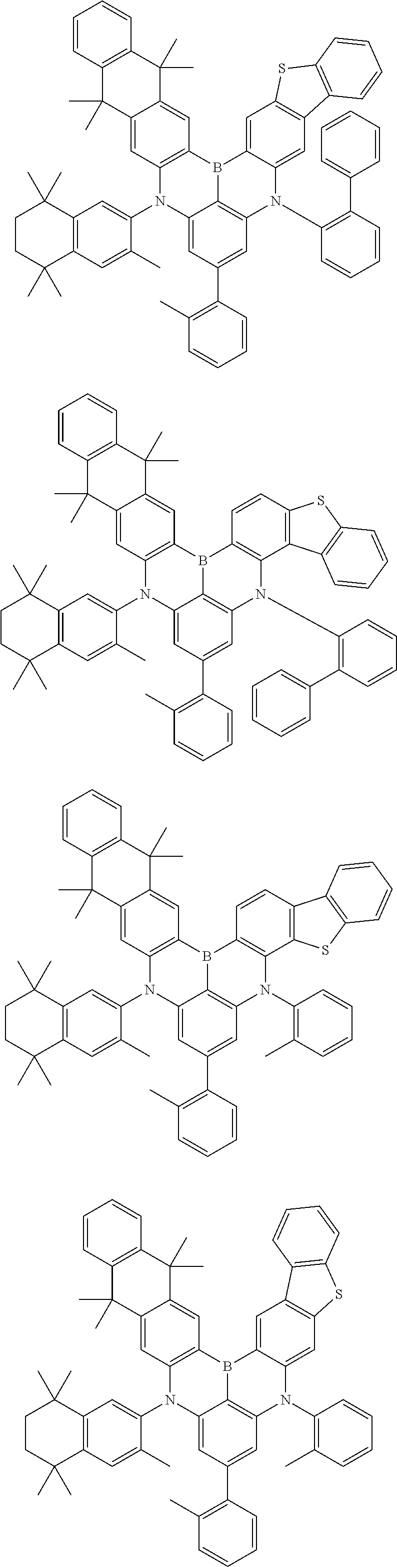 [SMILES: Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)c1ccccc1C3(C)C)sc1ccccc14 ; Cc1ccccc1-c1cc2c3c(c1)N(c1ccccc1-c1ccccc1)c1c(ccc4sc5ccccc5c14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1c(ccc4c1sc1ccccc14)B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4sc5ccccc5c4cc1B3c1cc3c(cc1N2c1cc2c(cc1C)C(C)(C)CCC2(C)C)C(C)(C)c1ccccc1C3(C)C]

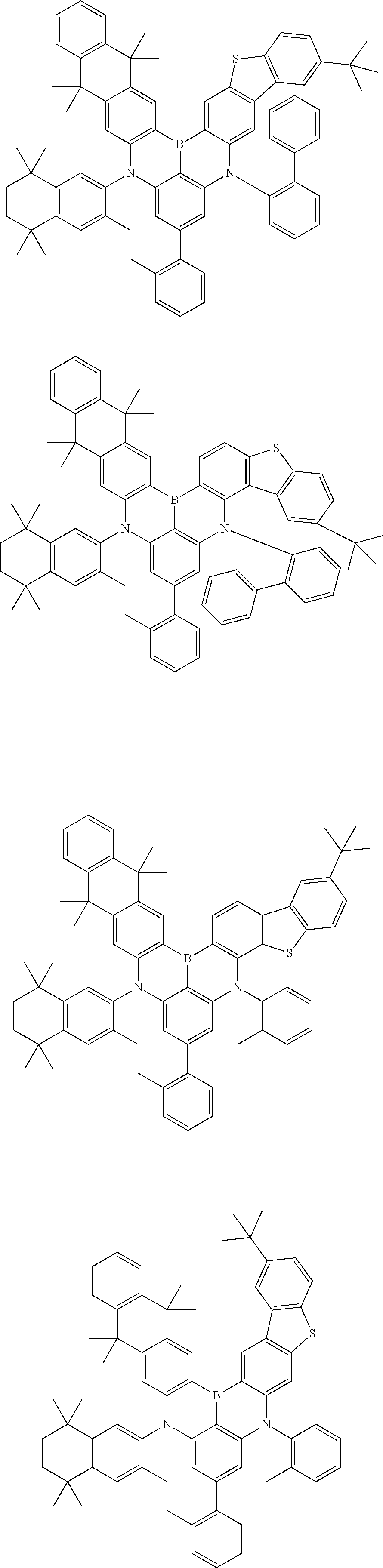

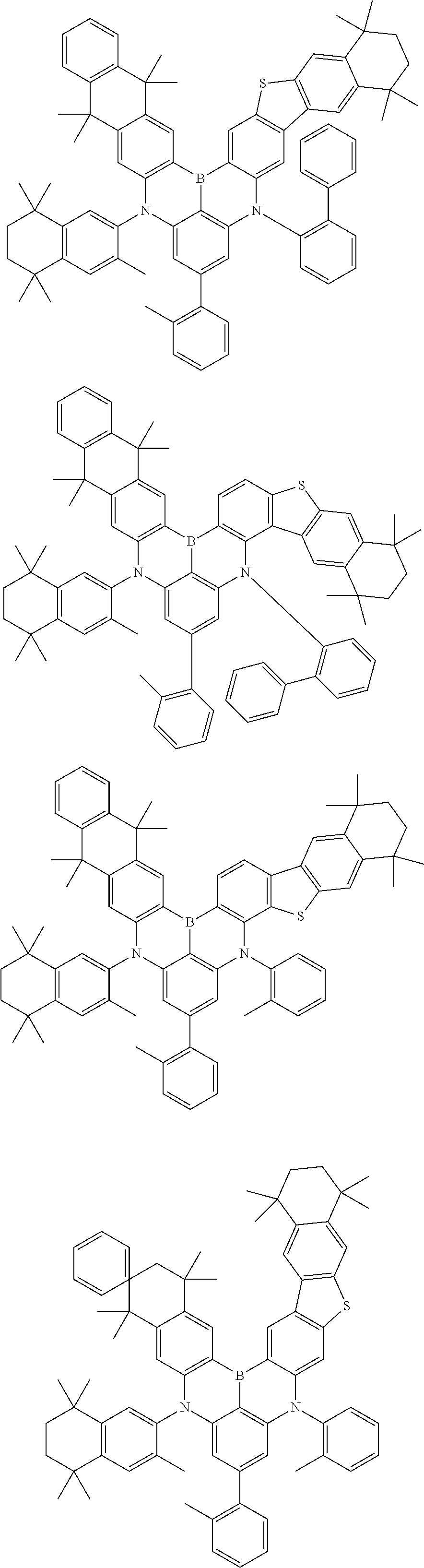

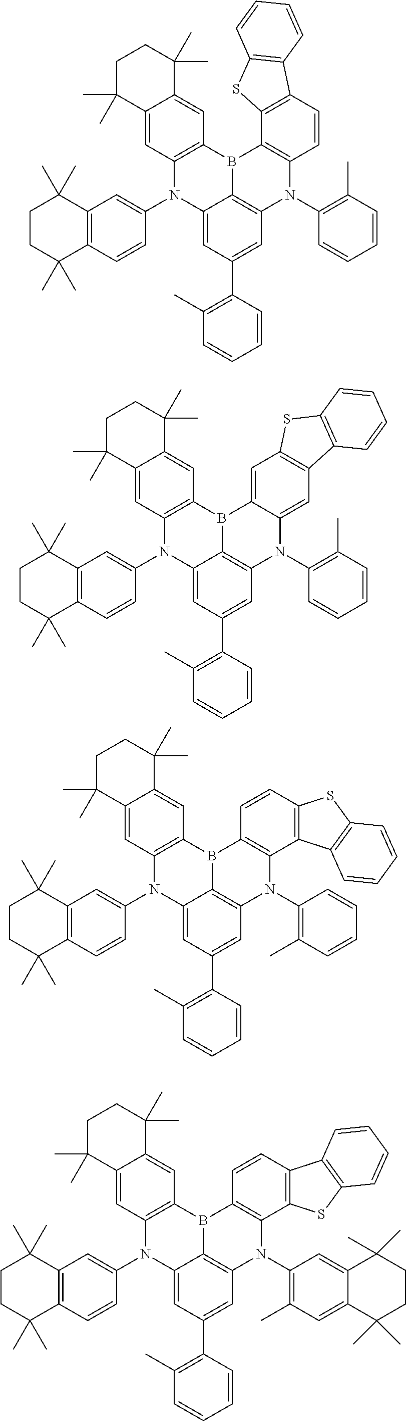

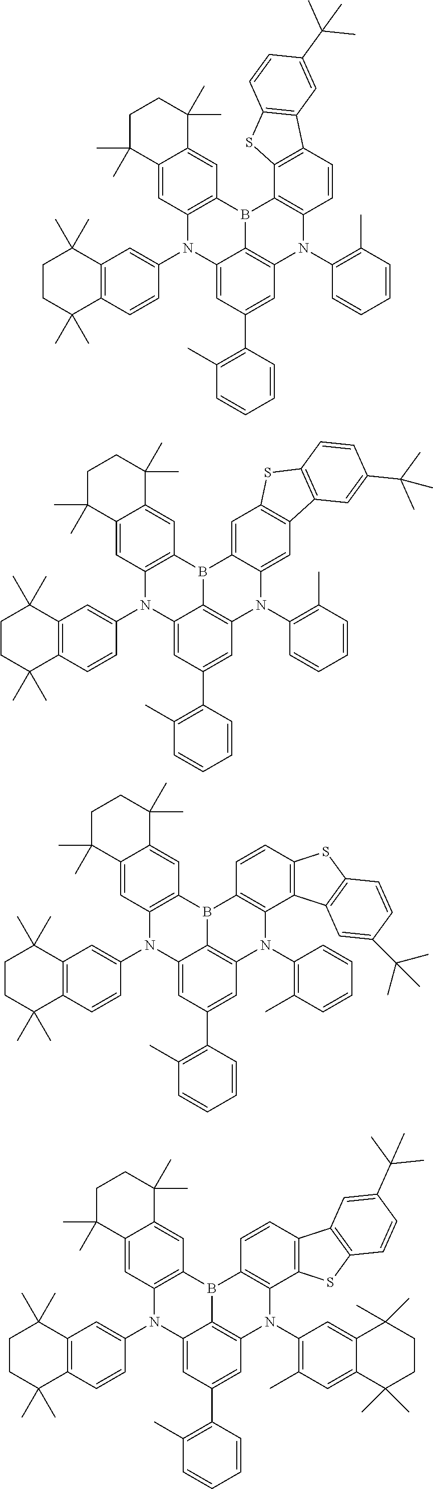

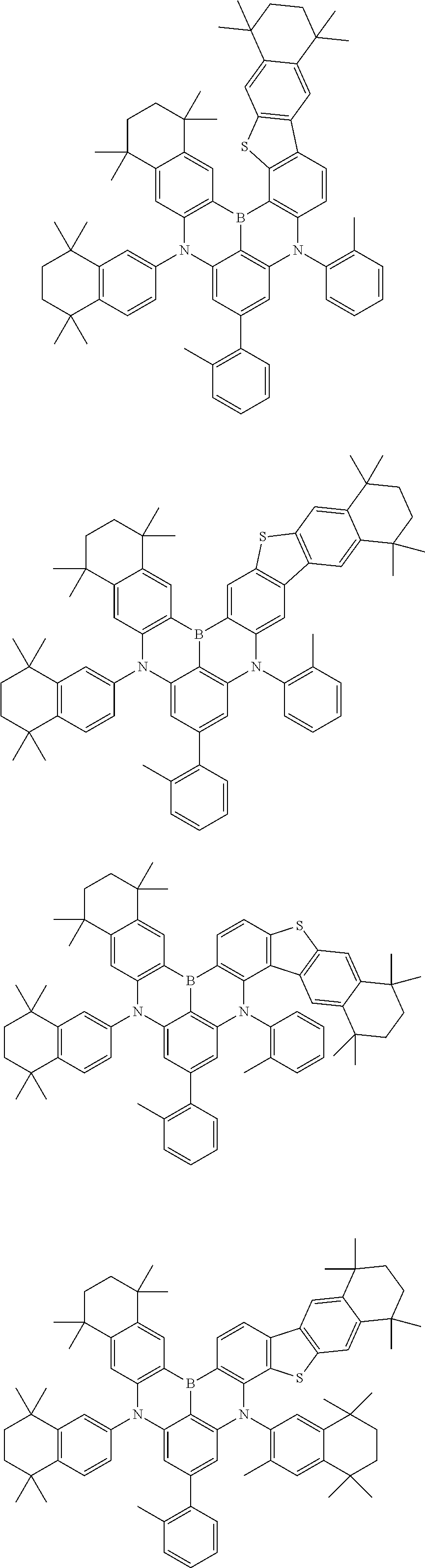

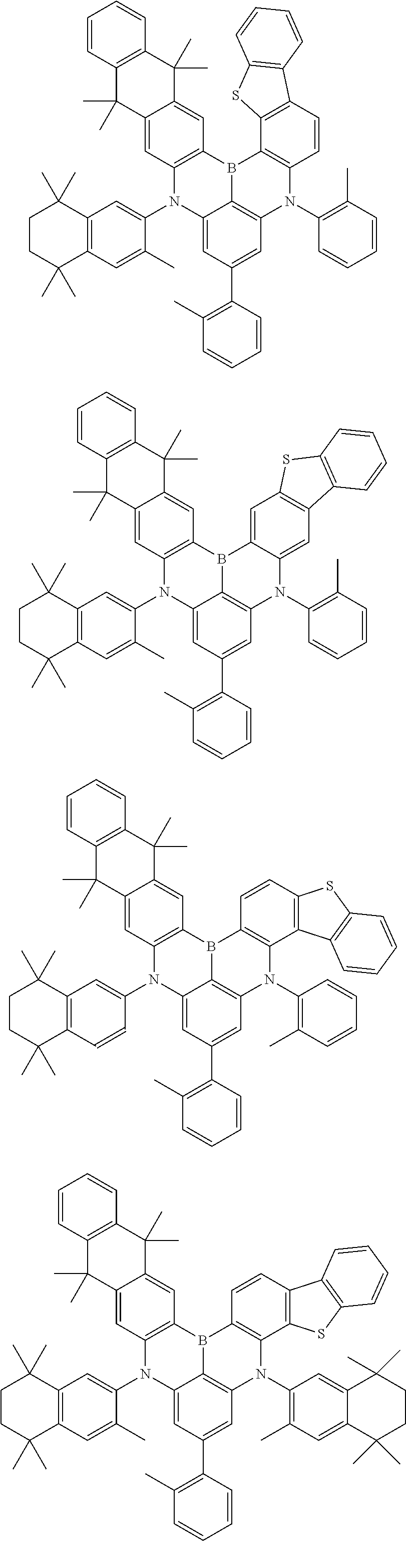 [SMILES: Cc1ccccc1-c1cc2c3c(c1)N(c1ccccc1C)c1ccc4c(sc5ccccc54)c1B3c1cc3c(cc1N2c1cc2c(cc1C)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)c1ccccc1C3(C)C)sc1ccccc14 ; Cc1ccccc1-c1cc2c3c(c1)N(c1ccccc1C)c1c(ccc4sc5ccccc5c14)B3c1cc3c(cc1N2c1ccc2c(c1)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1sc1ccccc14)B3c1cc3c(cc1N2c1cc2c(cc1C)C(C)(C)CCC2(C)C)C(C)(C)c1ccccc1C3(C)C]

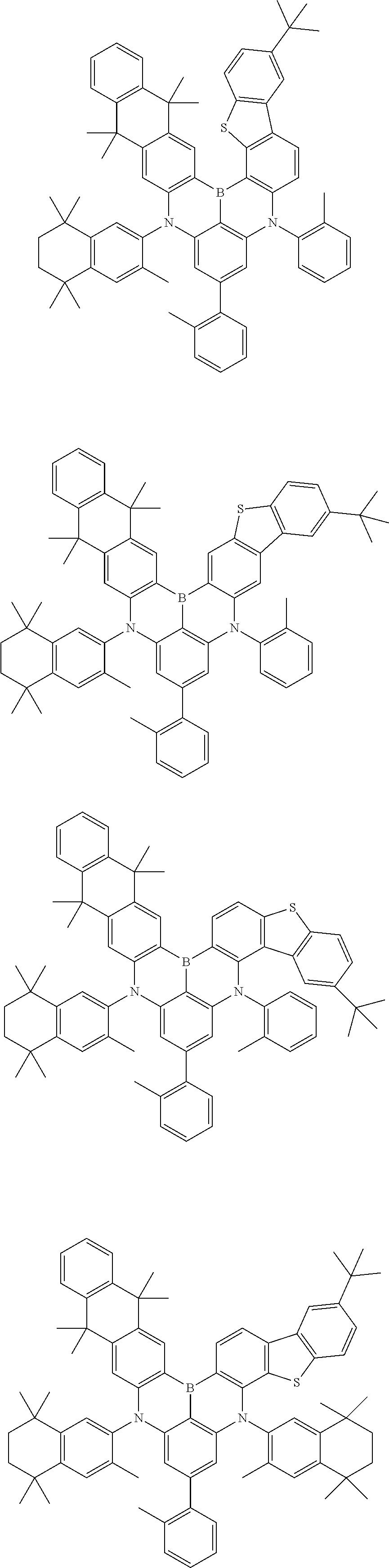

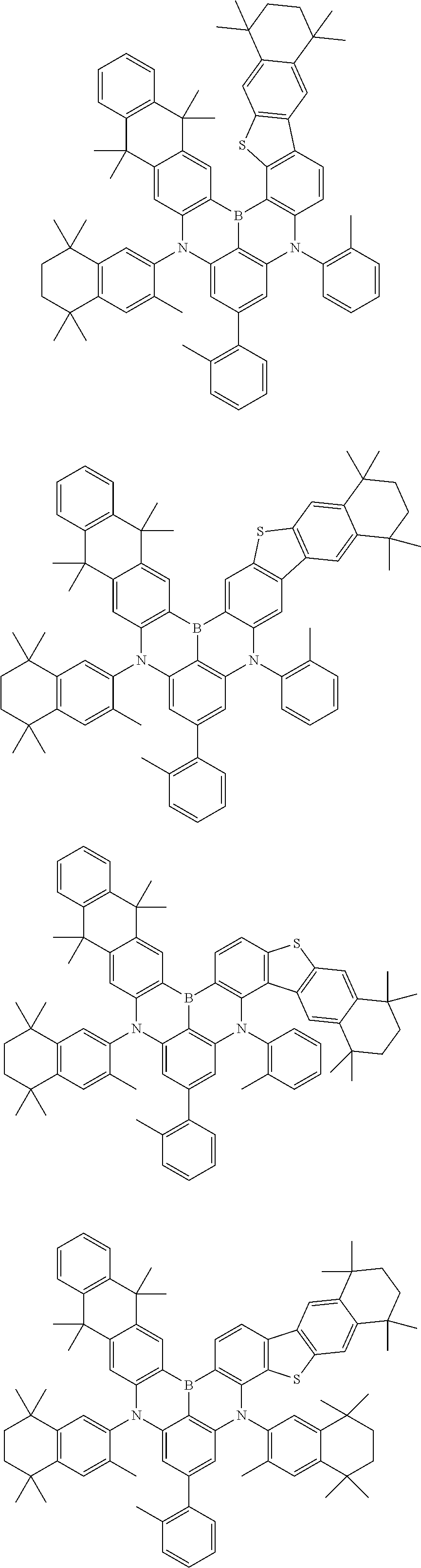

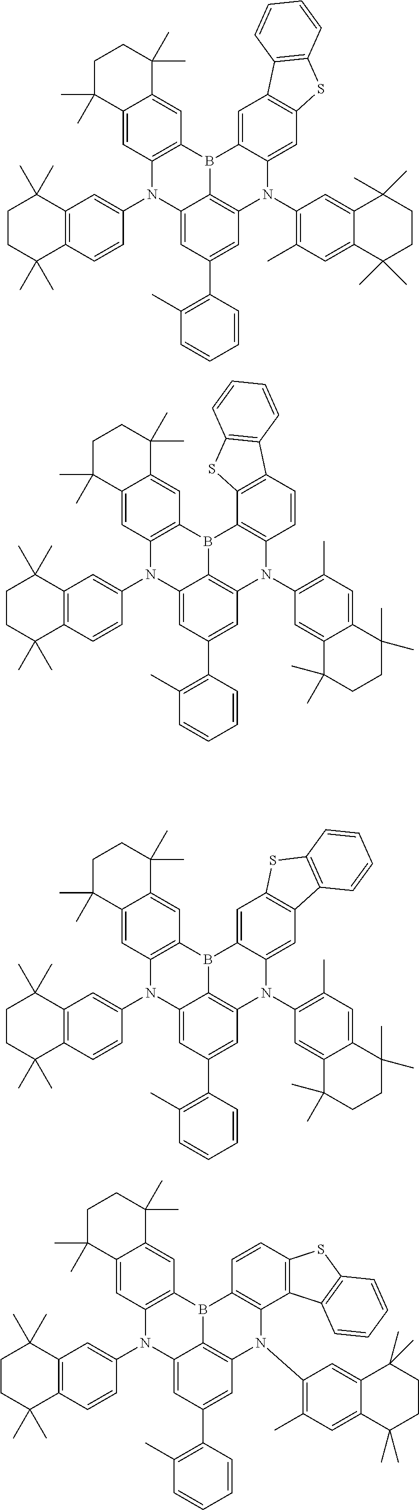

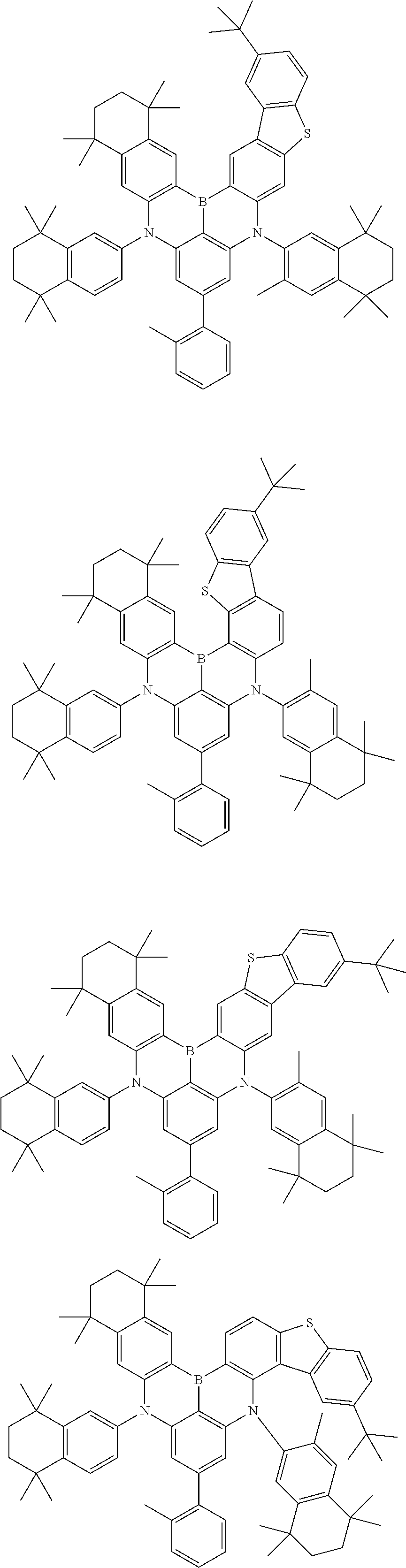

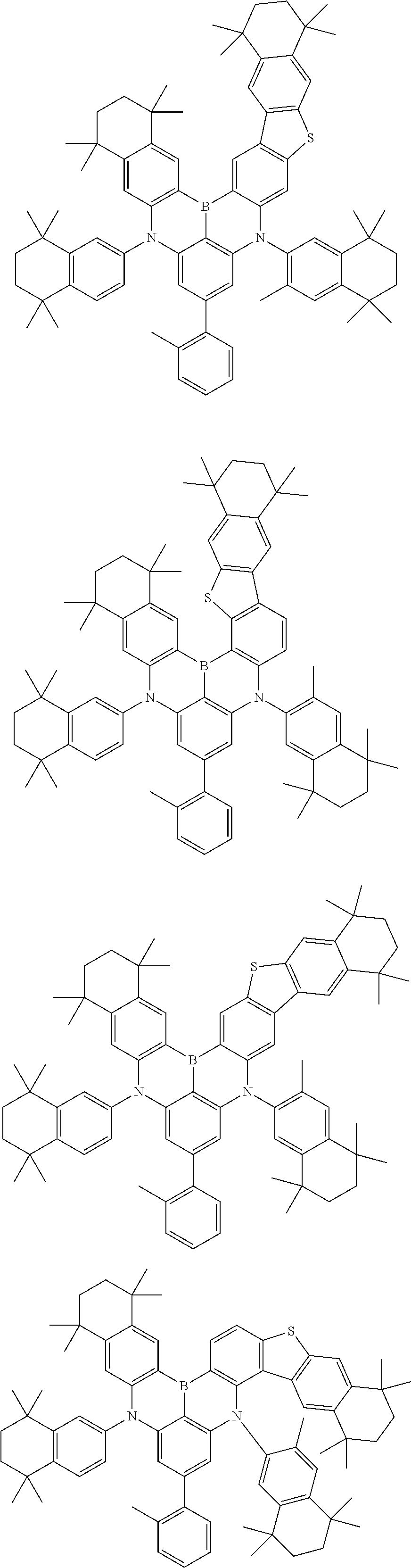

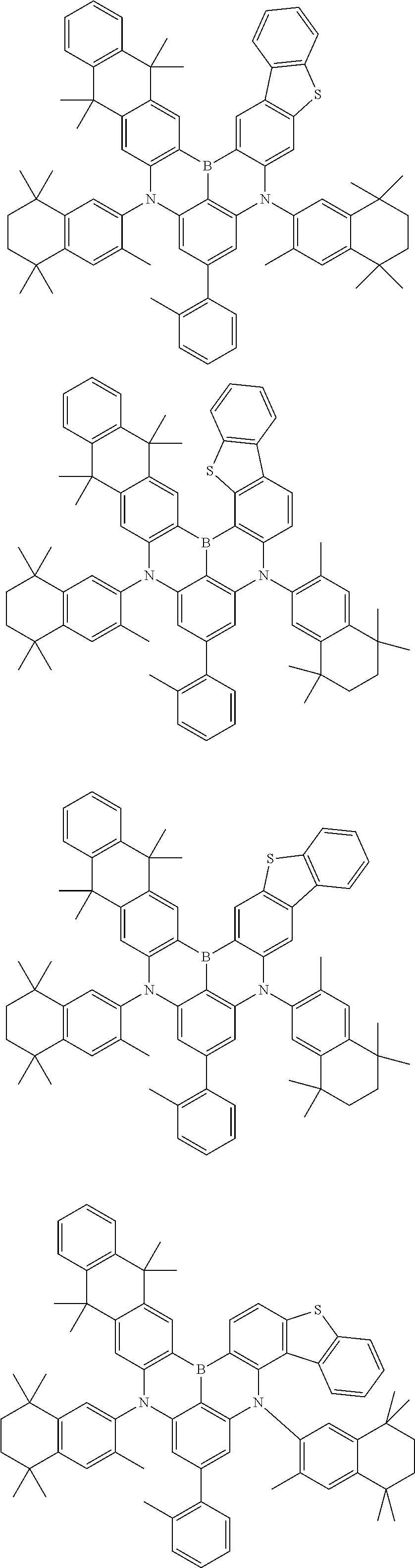

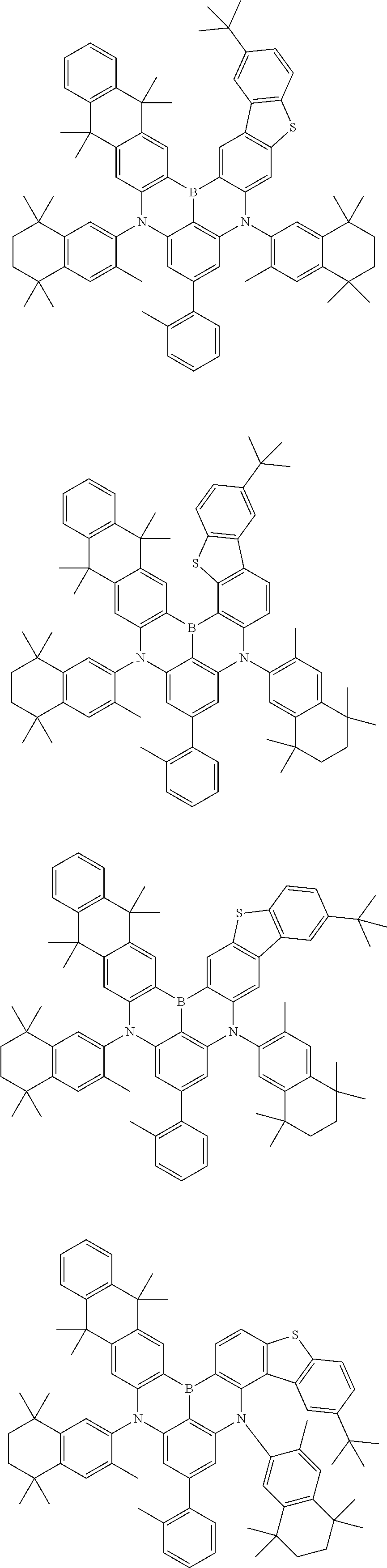

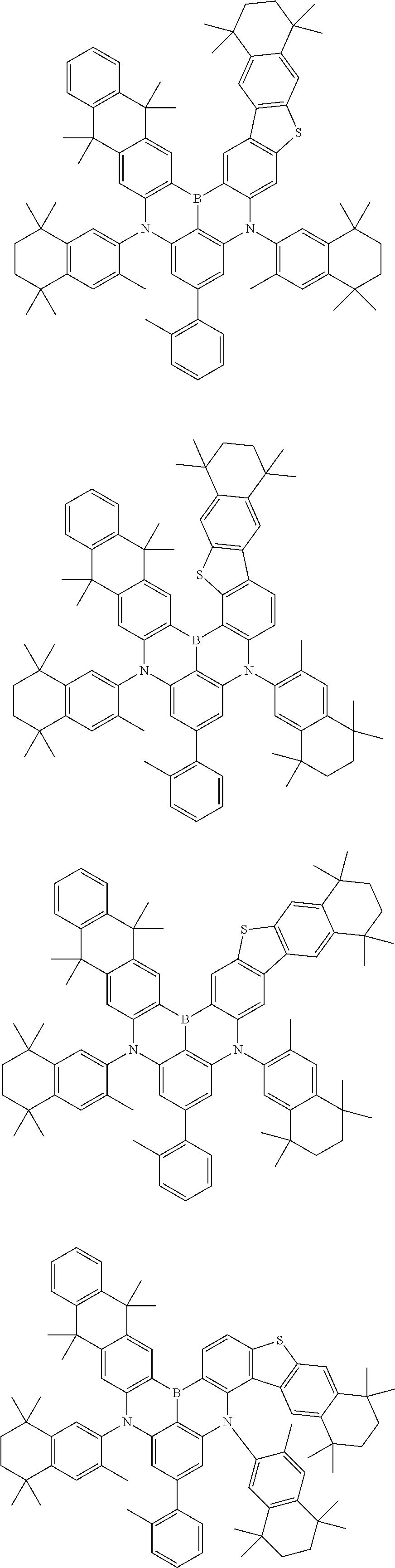

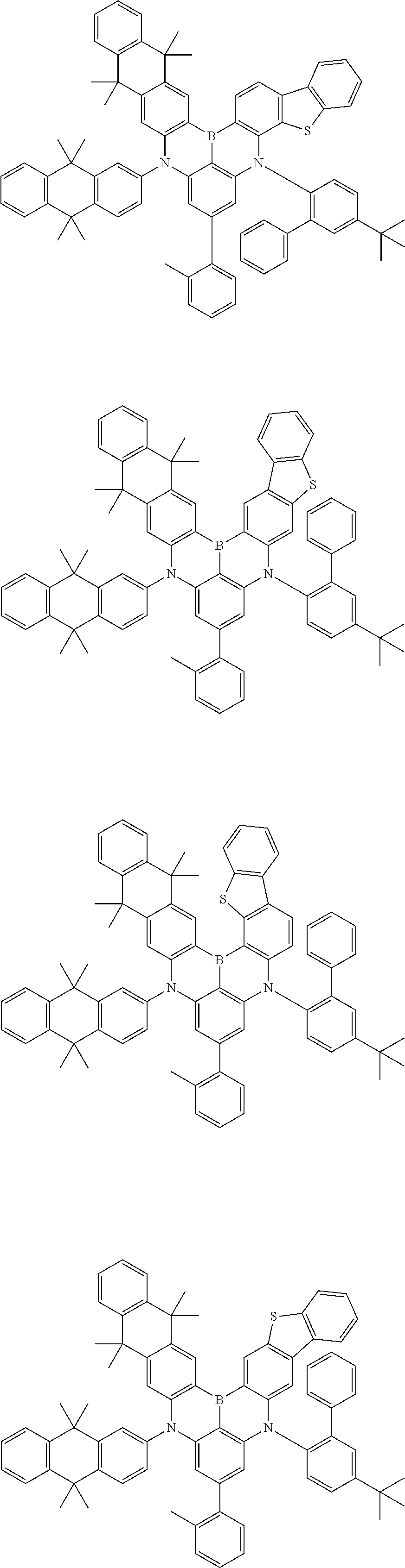

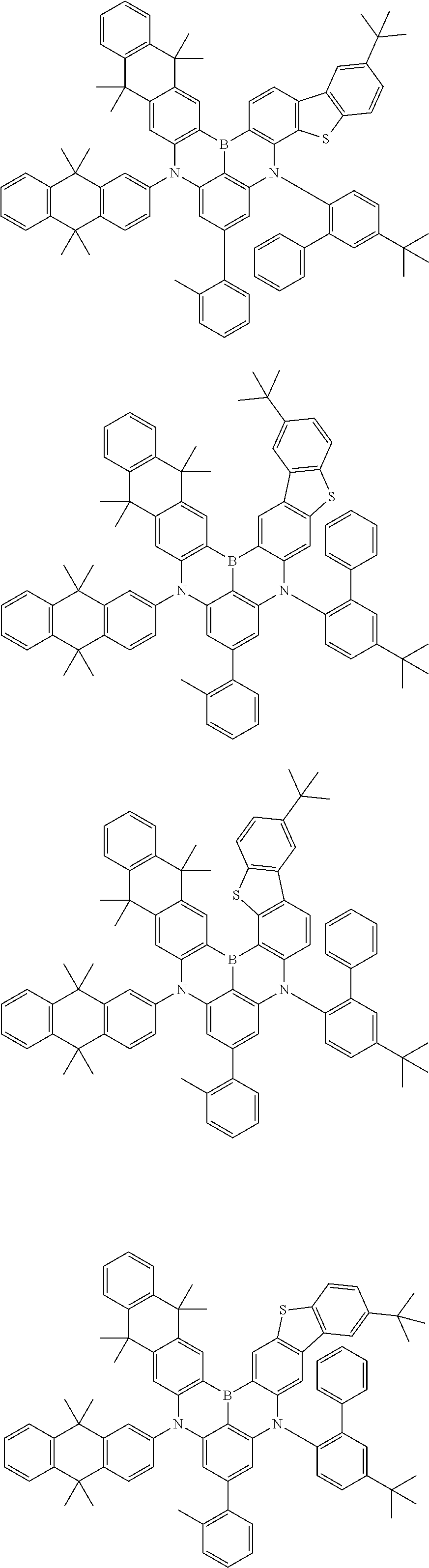

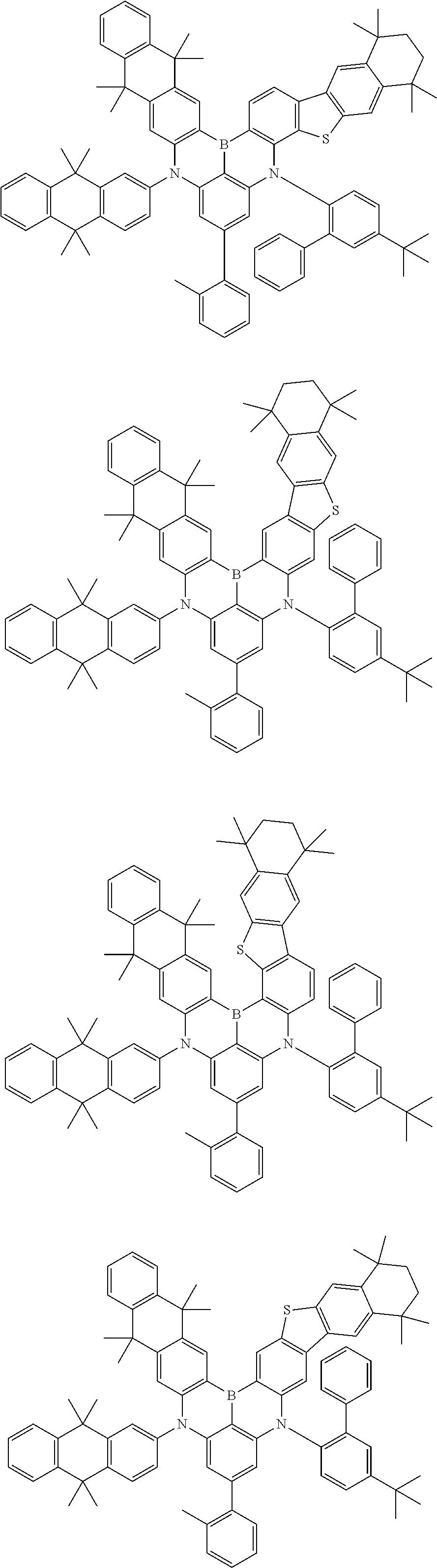

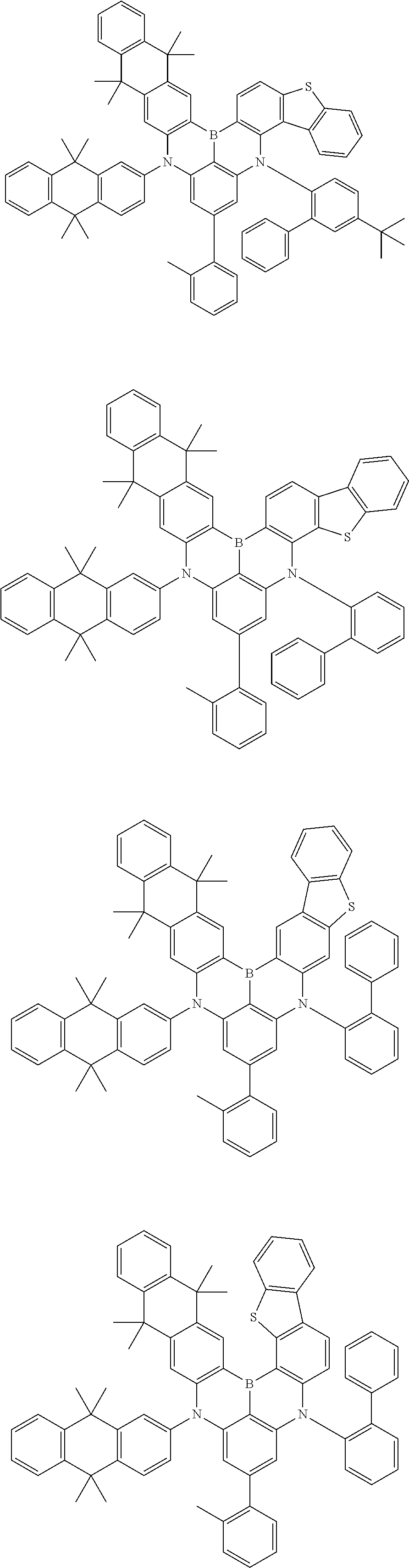

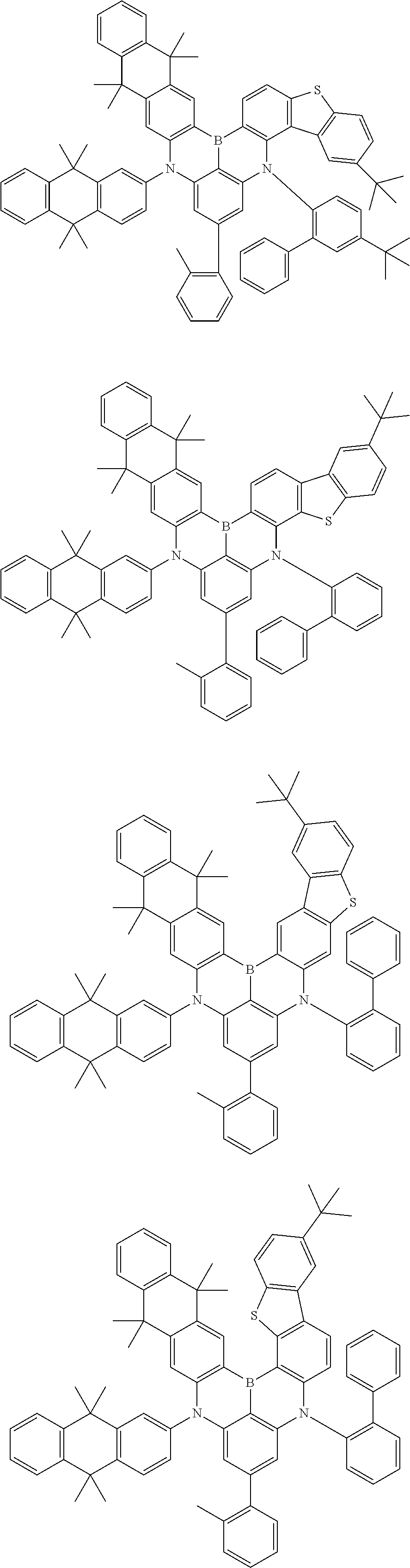

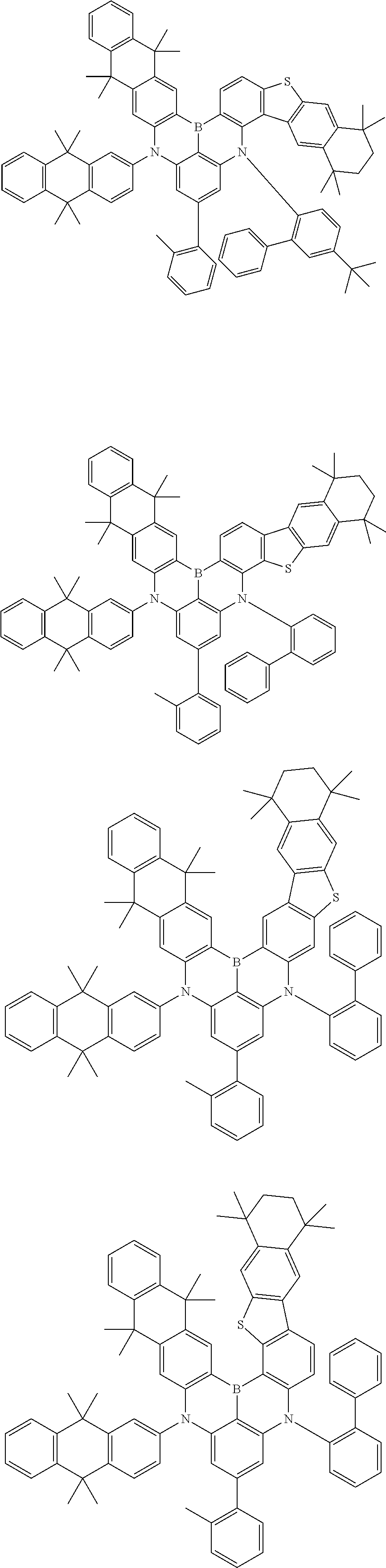

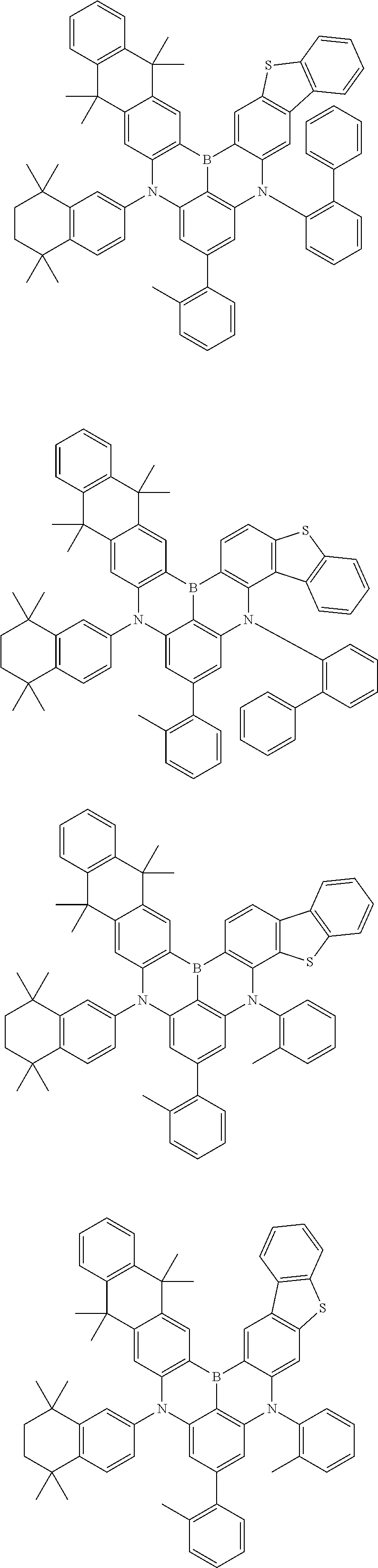 [SMILES: Cc1ccccc1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)c1ccccc1C3(C)C)sc1ccccc14 ; Cc1ccccc1-c1cc2c3c(c1)N(c1ccccc1-c1ccccc1)c1c(ccc4sc5ccccc5c14)B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccccc1C)c1c(ccc4c1sc1ccccc14)B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccccc1C)c1cc4sc5ccccc5c4cc1B3c1cc3c(cc1N2c1ccc2c(c1)C(C)(C)CCC2(C)C)C(C)(C)c1ccccc1C3(C)C]

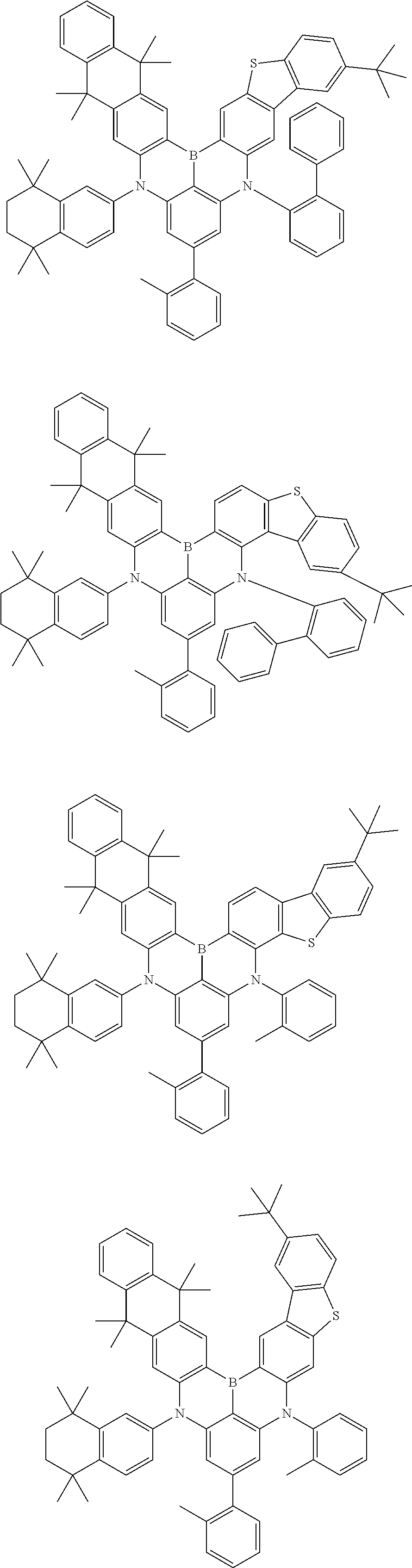

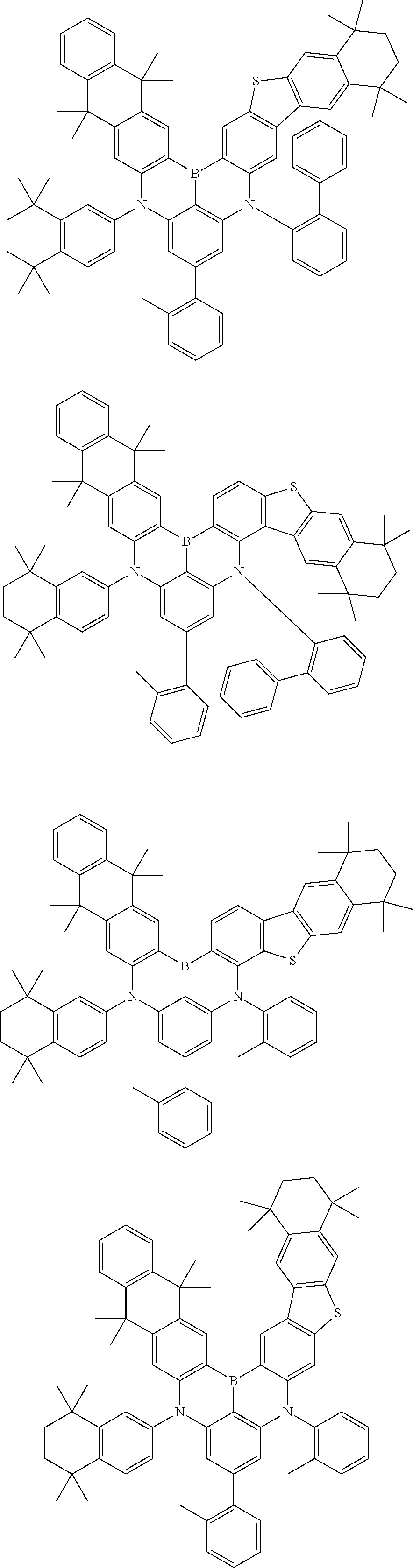

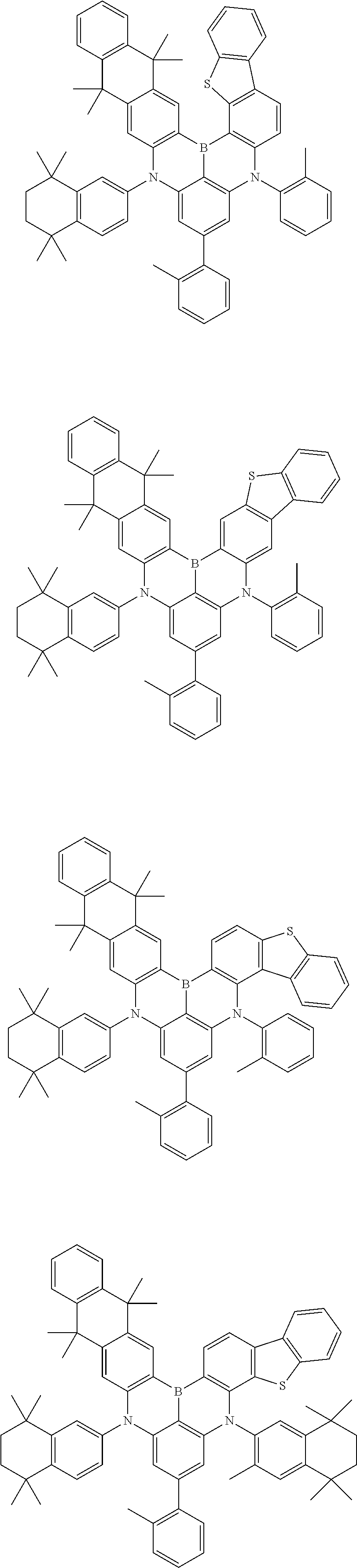 [SMILES: Cc1ccccc1-c1cc2c3c(c1)N(c1ccccc1C)c1ccc4c(sc5ccccc54)c1B3c1cc3c(cc1N2c1ccc2c(c1)C(C)(C)CCC2(C)C)C(C)(C)c1ccccc1C3(C)C ; Cc1ccccc1-c1cc2c3c(c1)N(c1ccccc1C)c1cc4c(cc1B3c1cc3c(cc1N2c1ccc2c(c1)C(C)(C)CCC2(C)C)C(C)(C)c1ccccc1C3(C)C)sc1ccccc14 ; Cc1ccccc1-c1cc2c3c(c1)N(c1ccccc1C)c1c(ccc4sc5ccccc5c14)B3c1cc3c(cc1N2c1ccc2c(c1)C(C)(C)CCC2(C)C)C(C)(C)c1ccccc1C3(C)C ; Cc1ccccc1-c1cc2c3c(c1)N(c1cc4c(cc1C)C(C)(C)CCC4(C)C)c1c(ccc4c1sc1ccccc14)B3c1cc3c(cc1N2c1ccc2c(c1)C(C)(C)CCC2(C)C)C(C)(C)c1ccccc1C3(C)C]

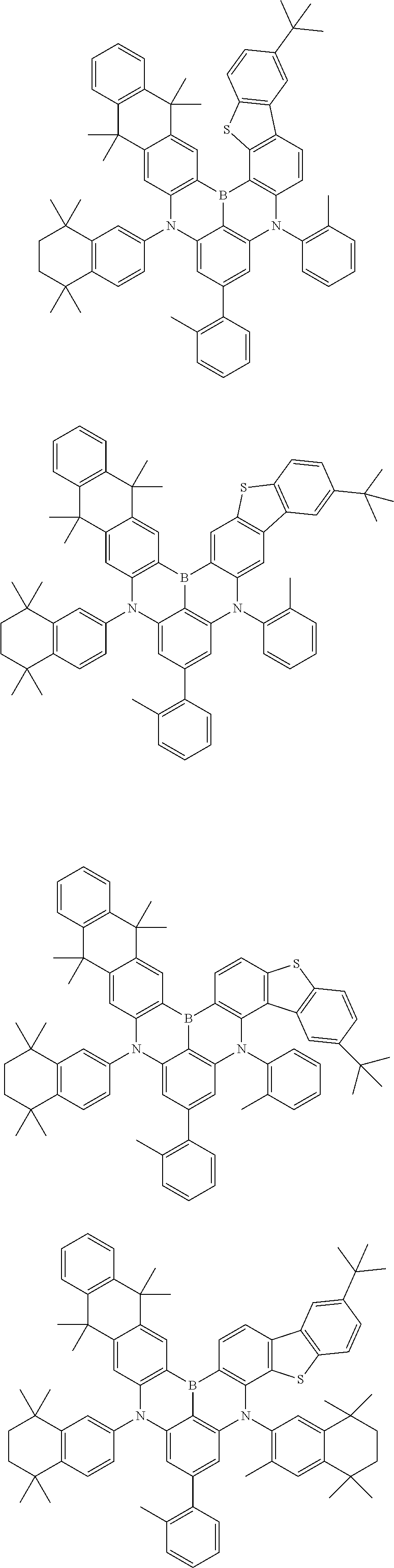

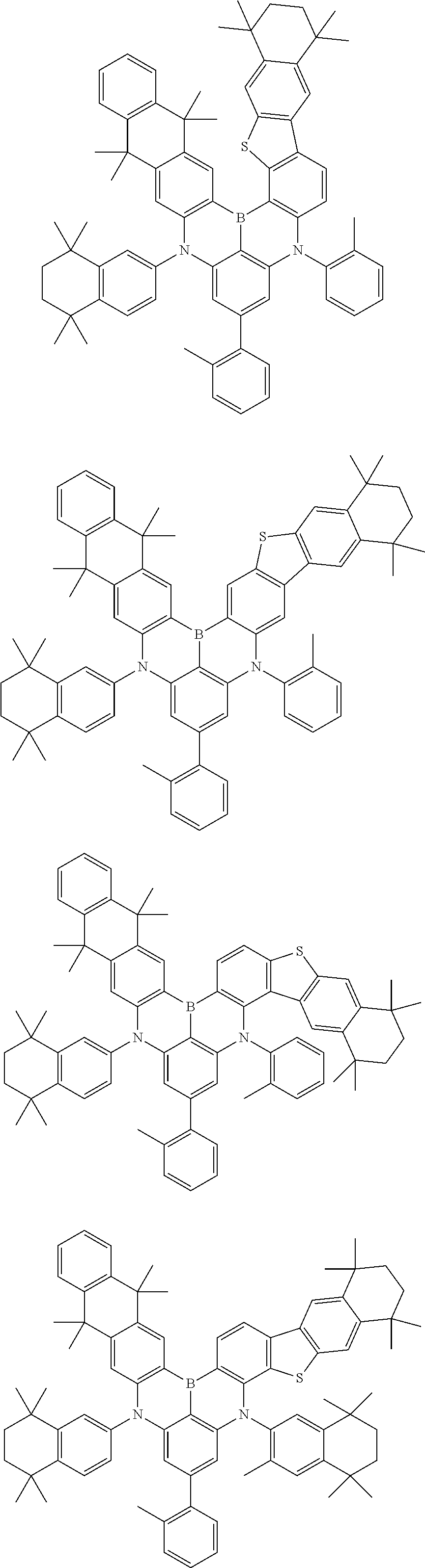

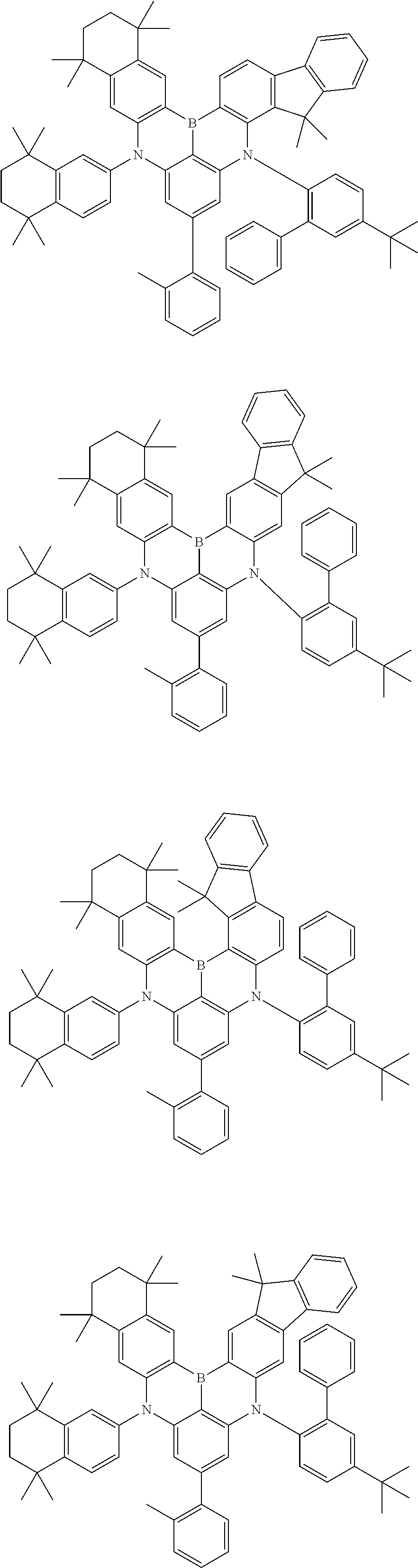

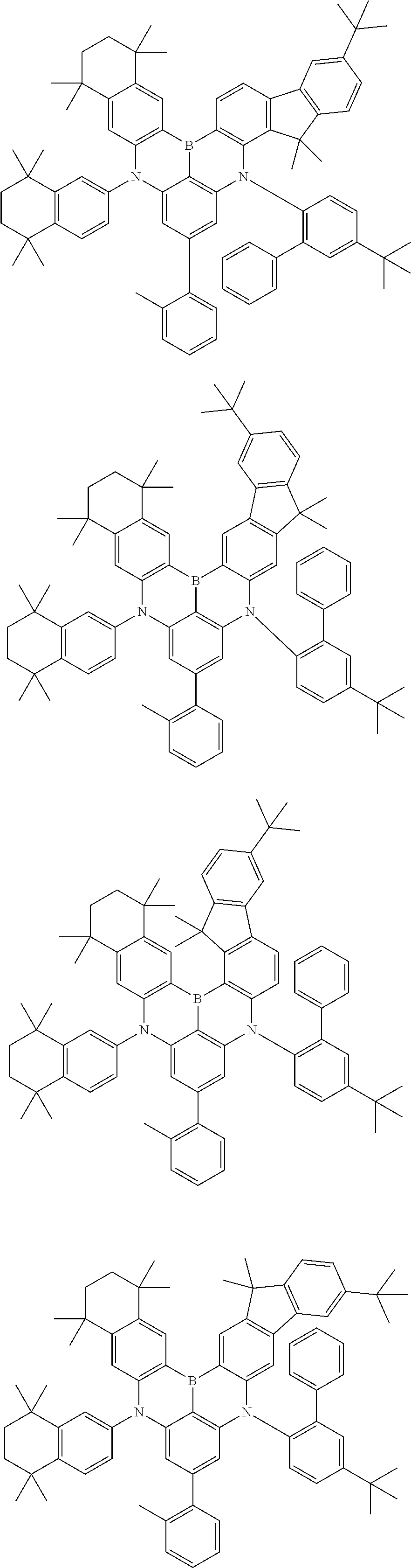

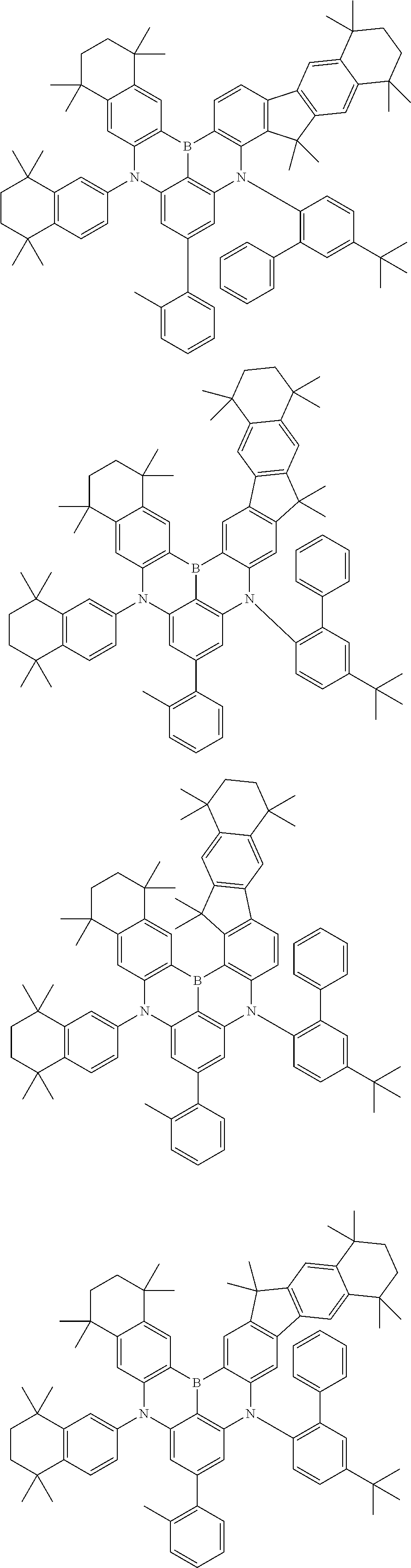

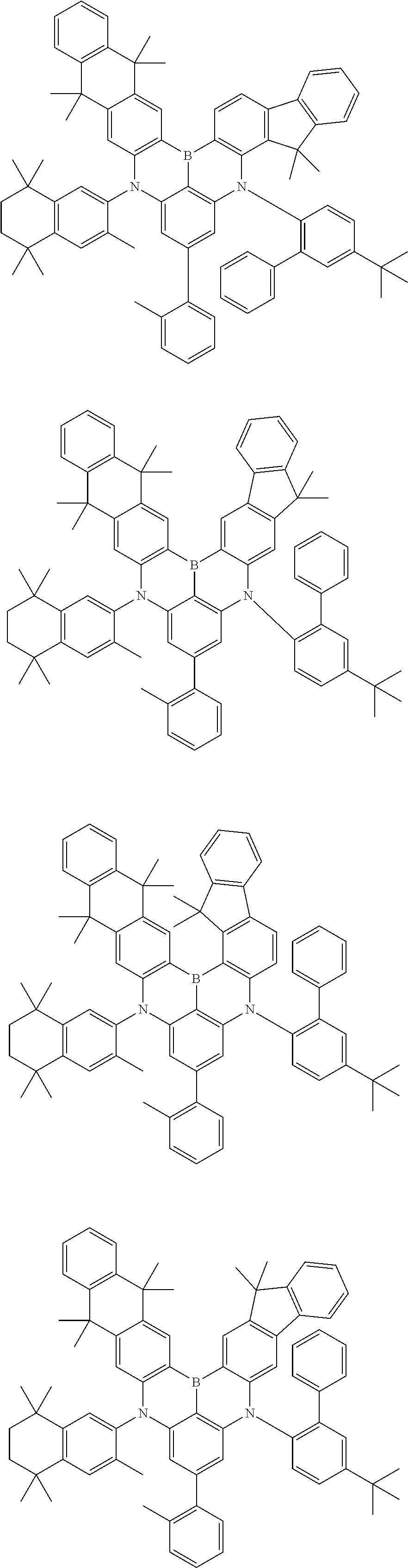

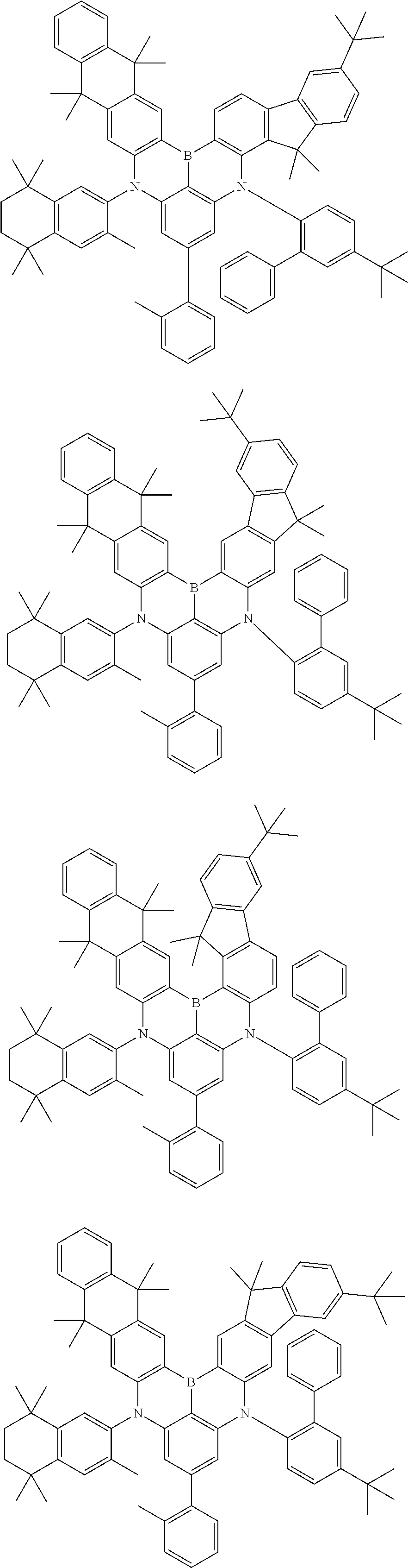

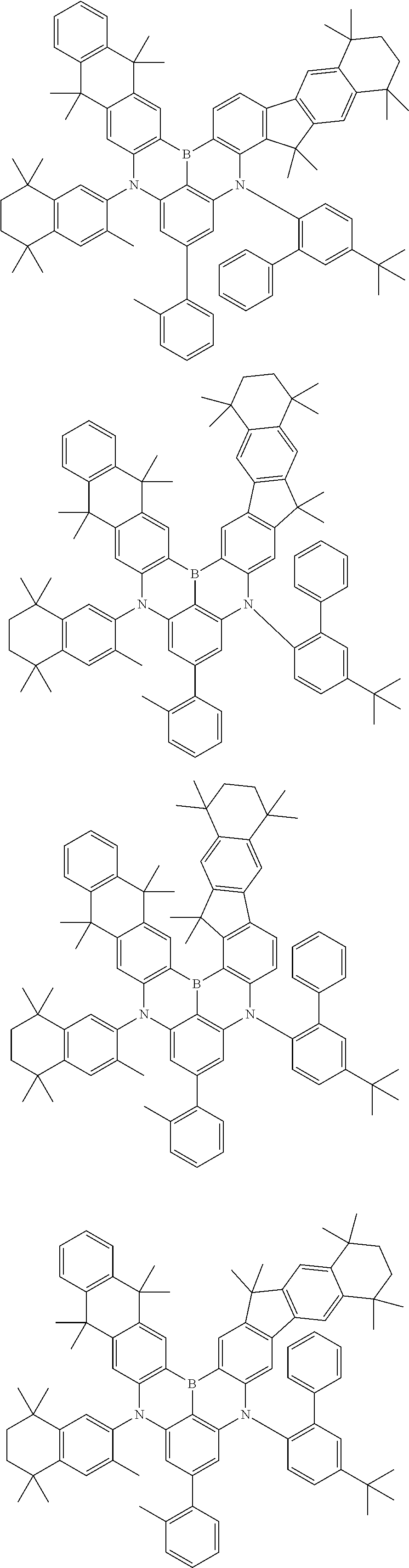

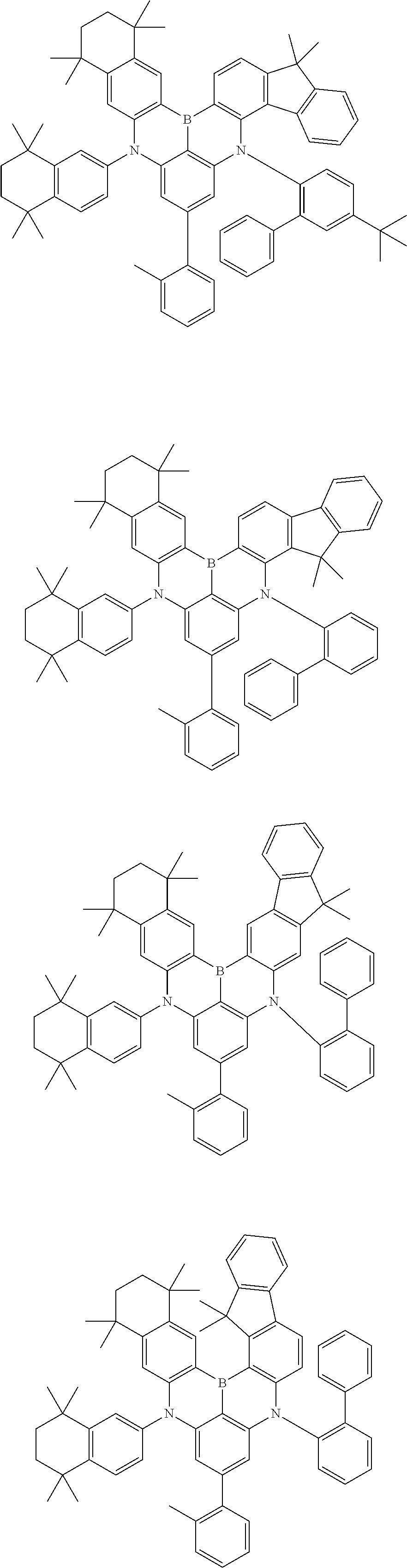

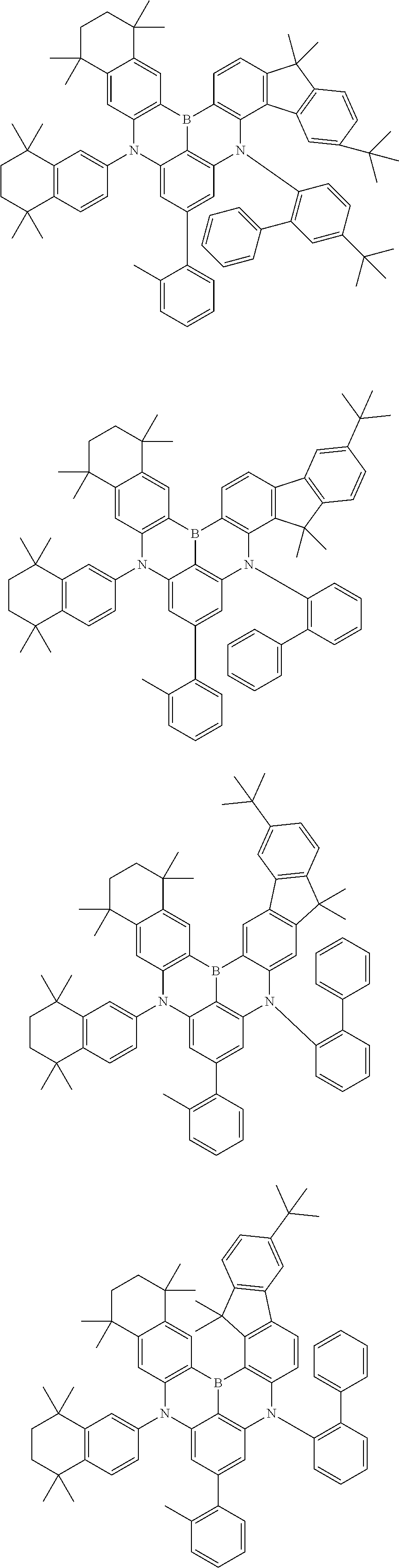

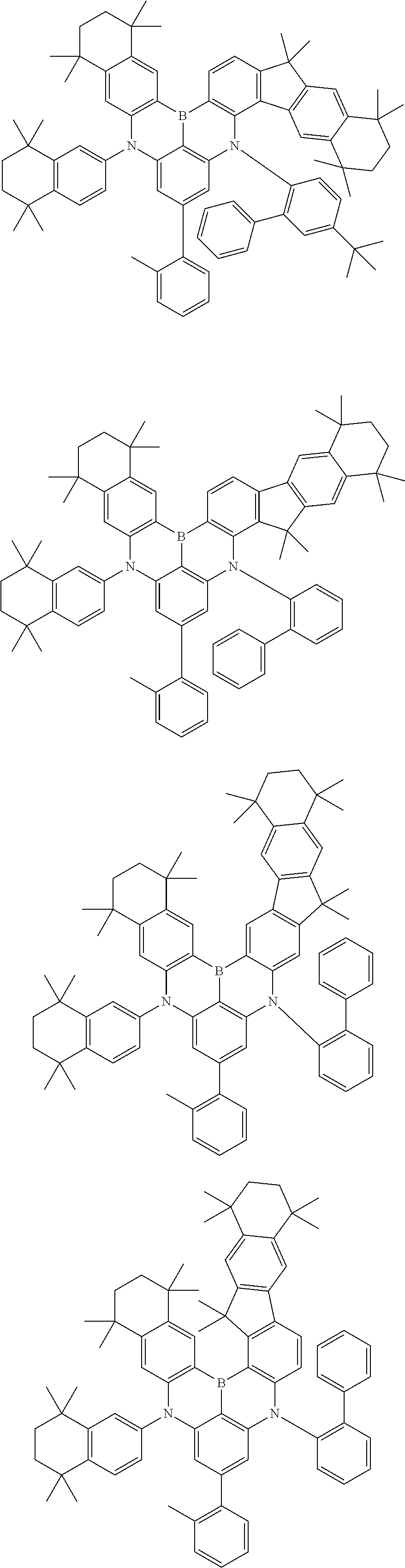

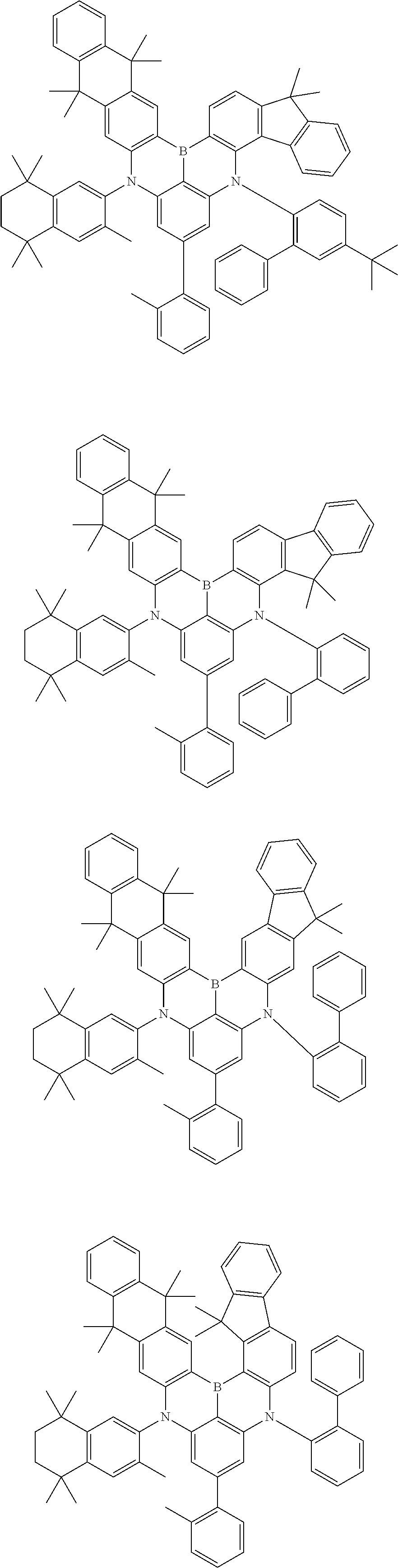

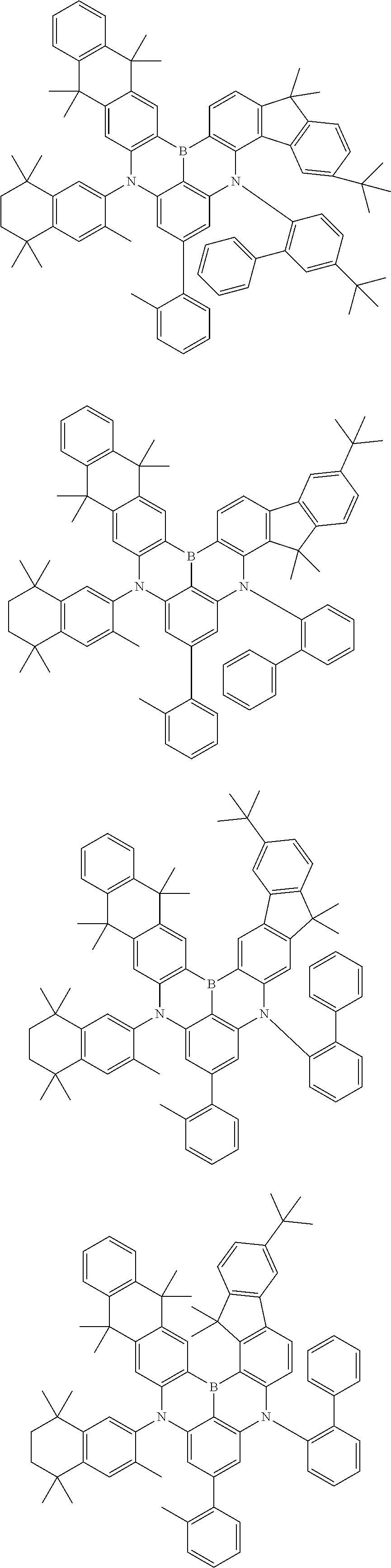

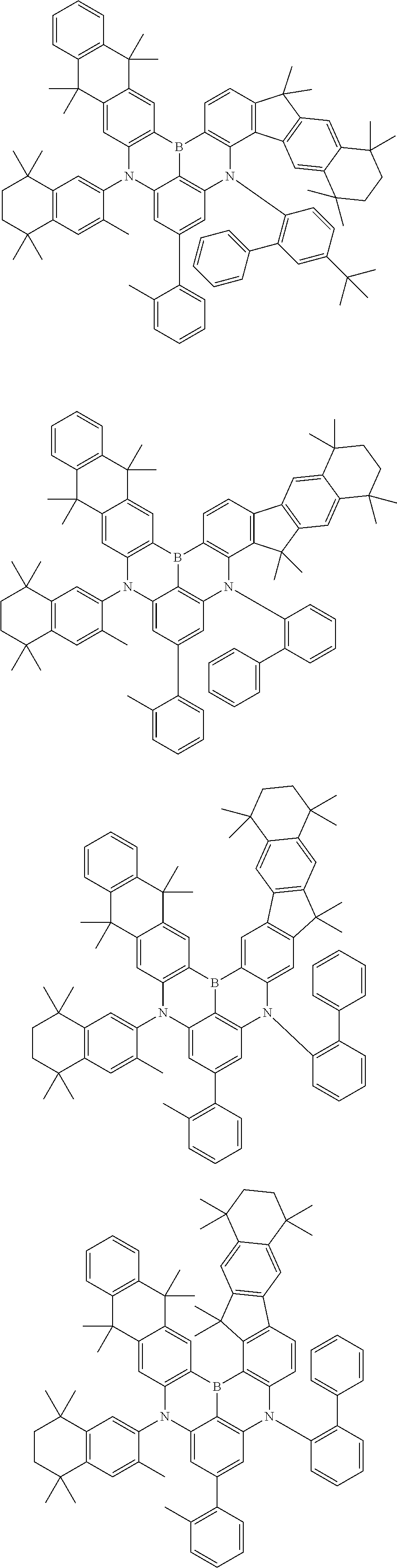

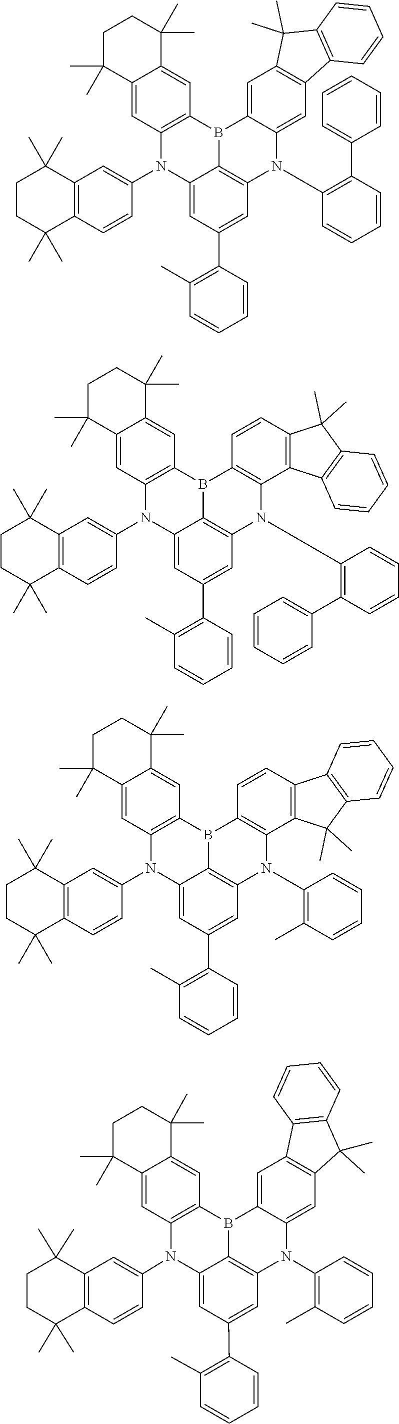

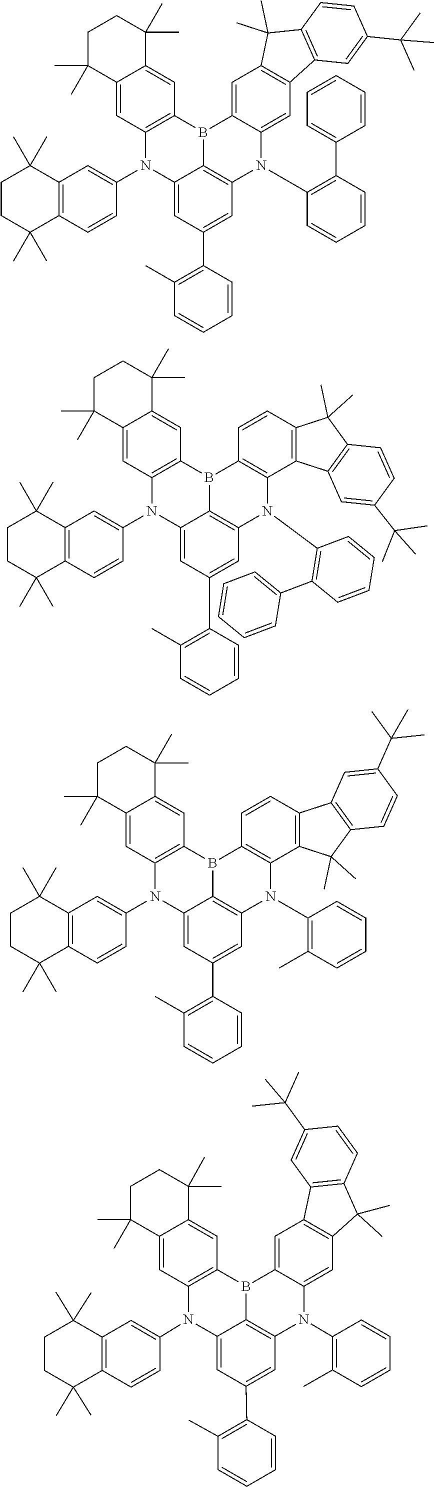

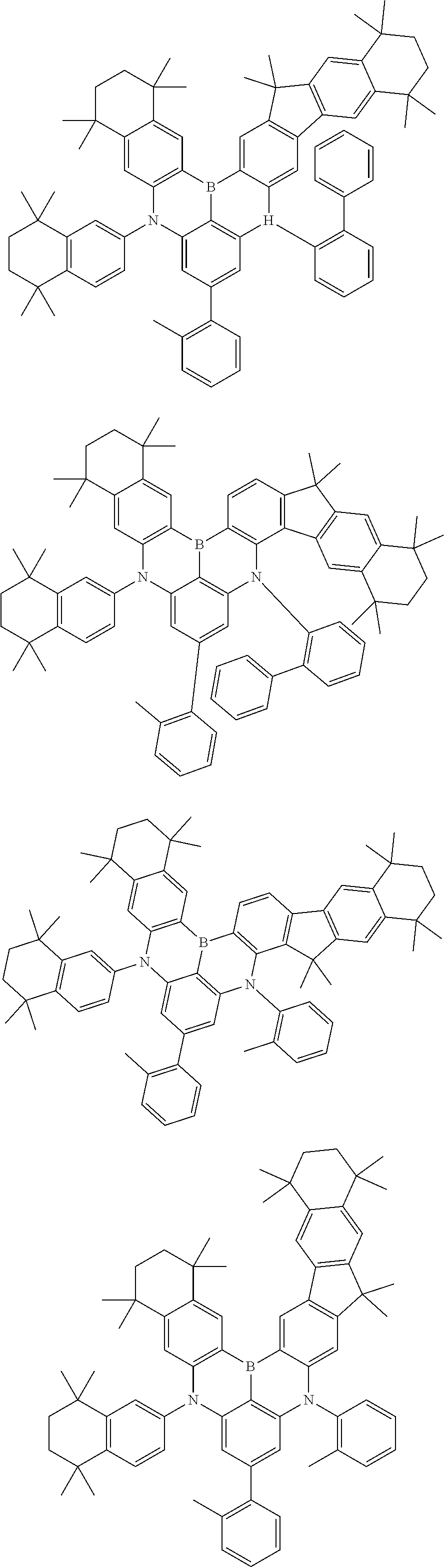

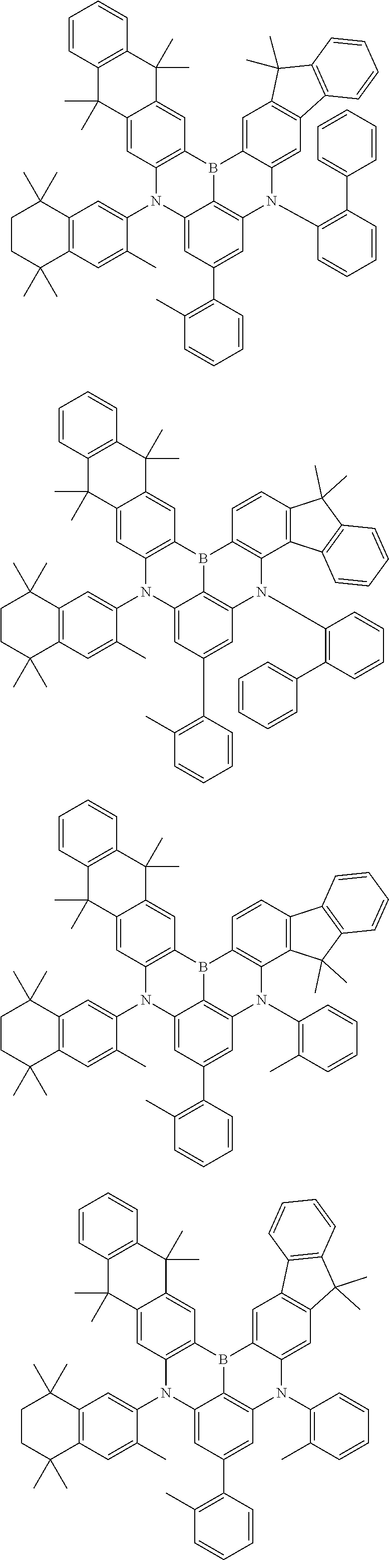

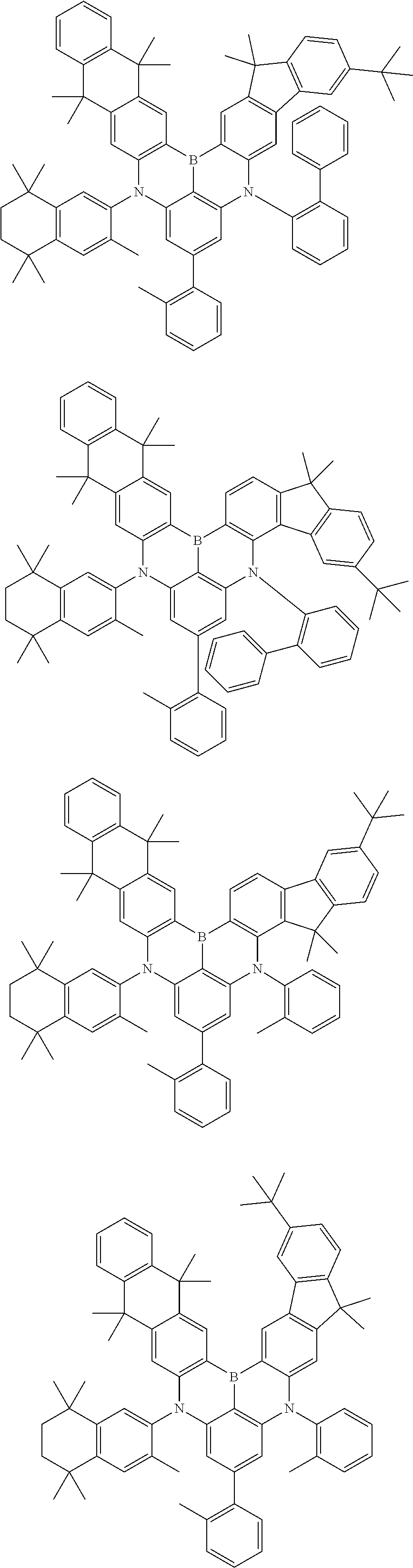

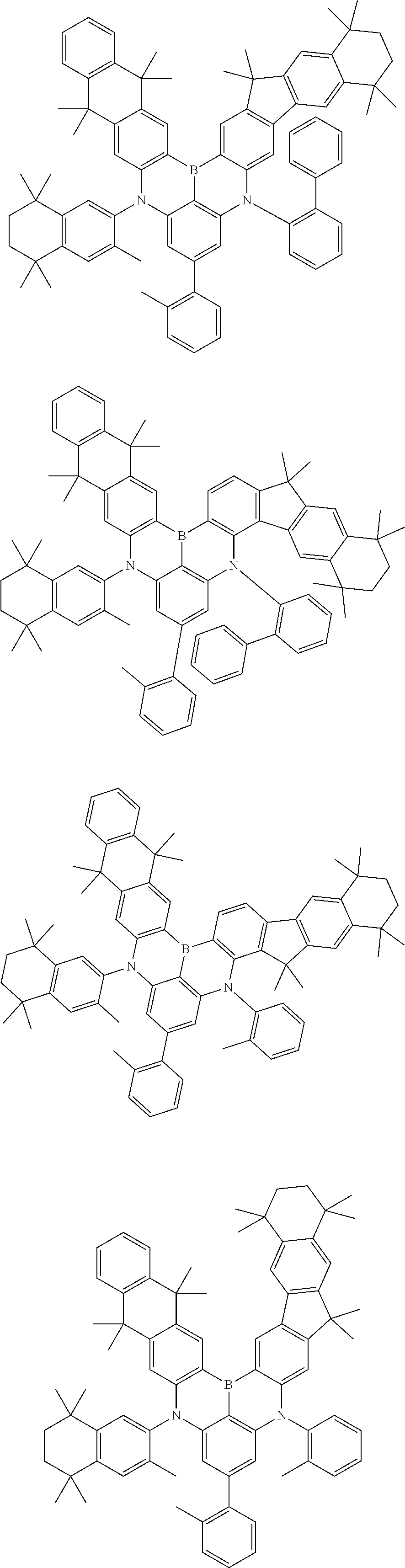

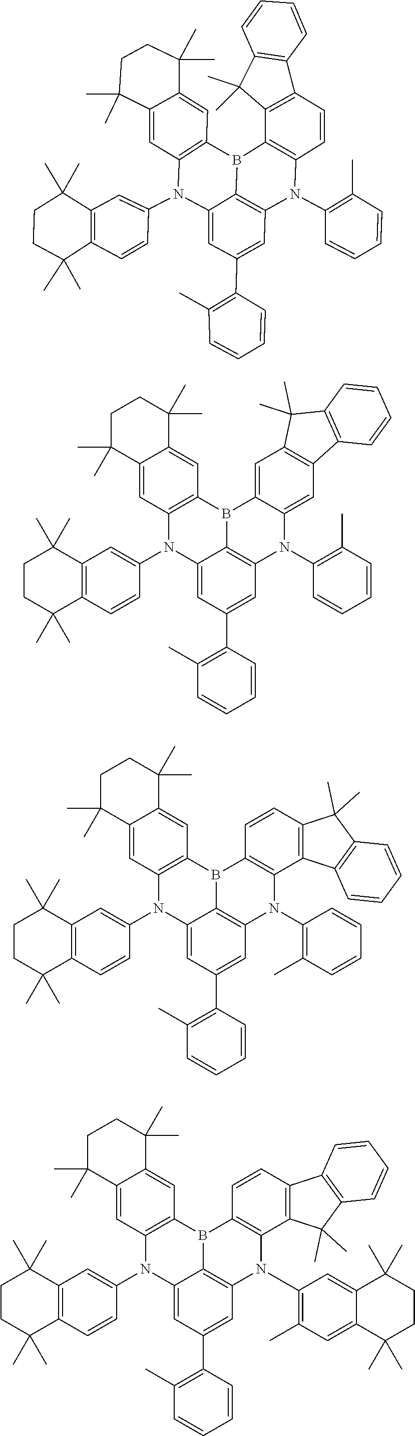

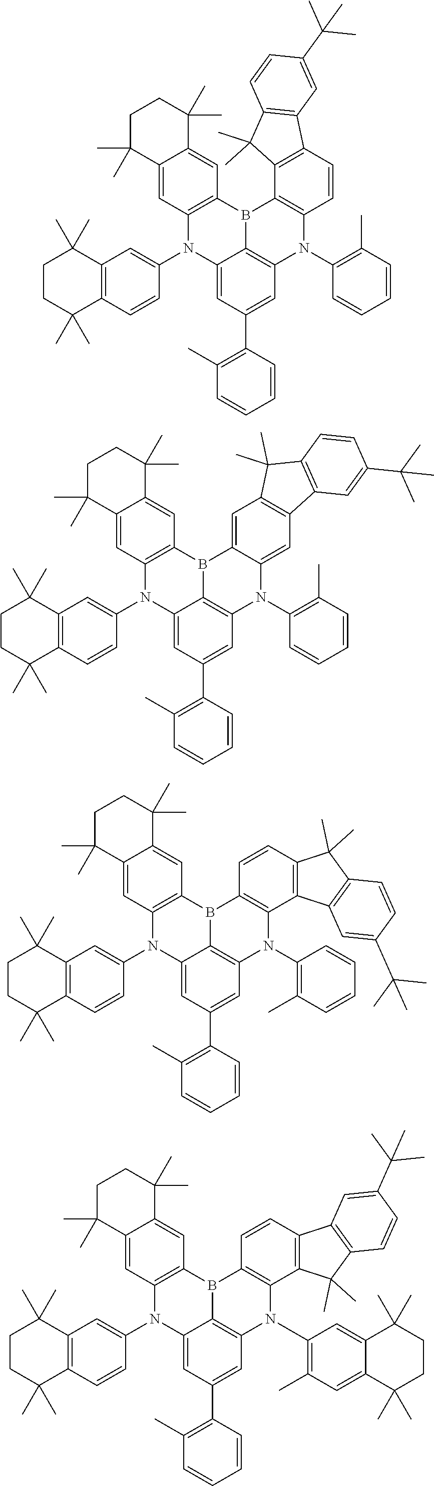

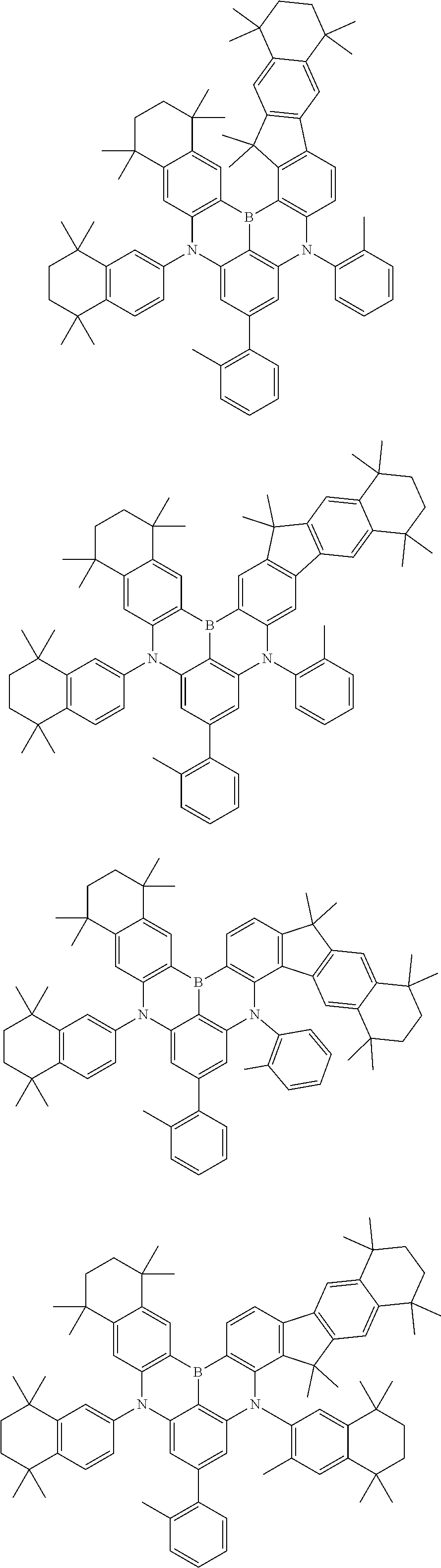

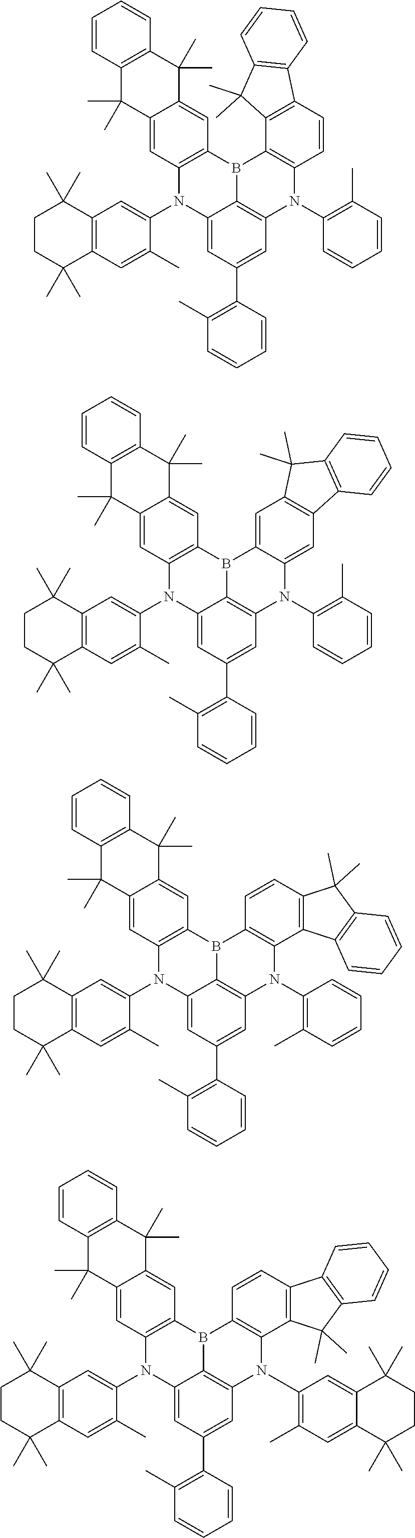

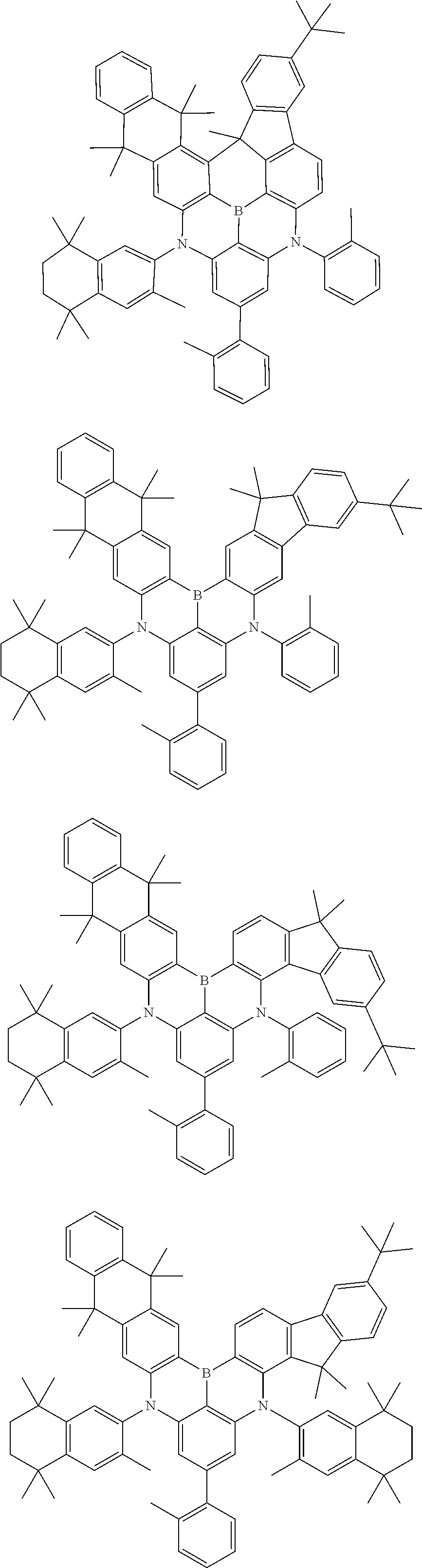

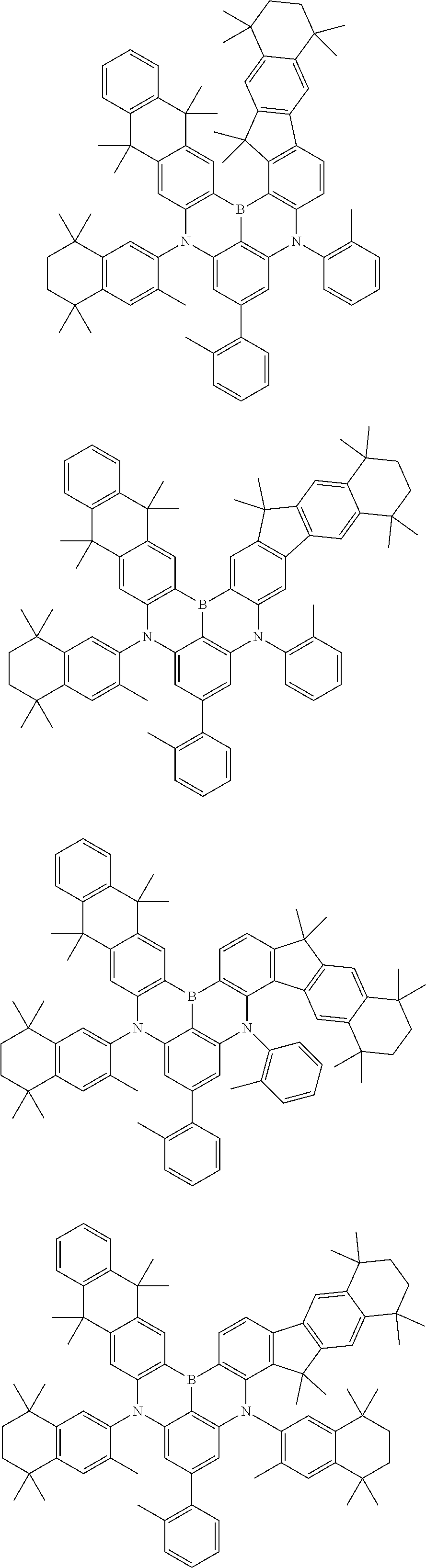

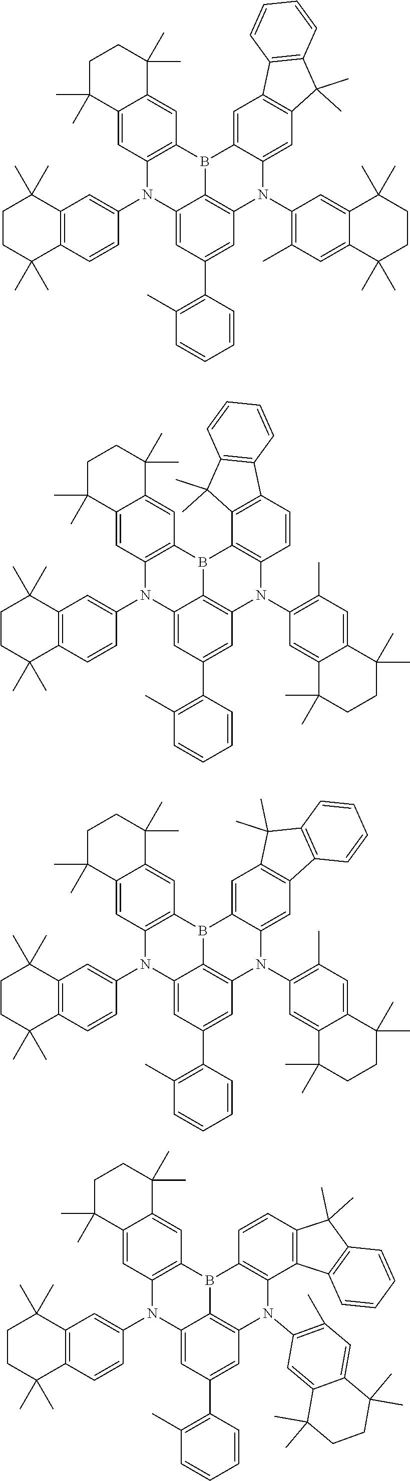

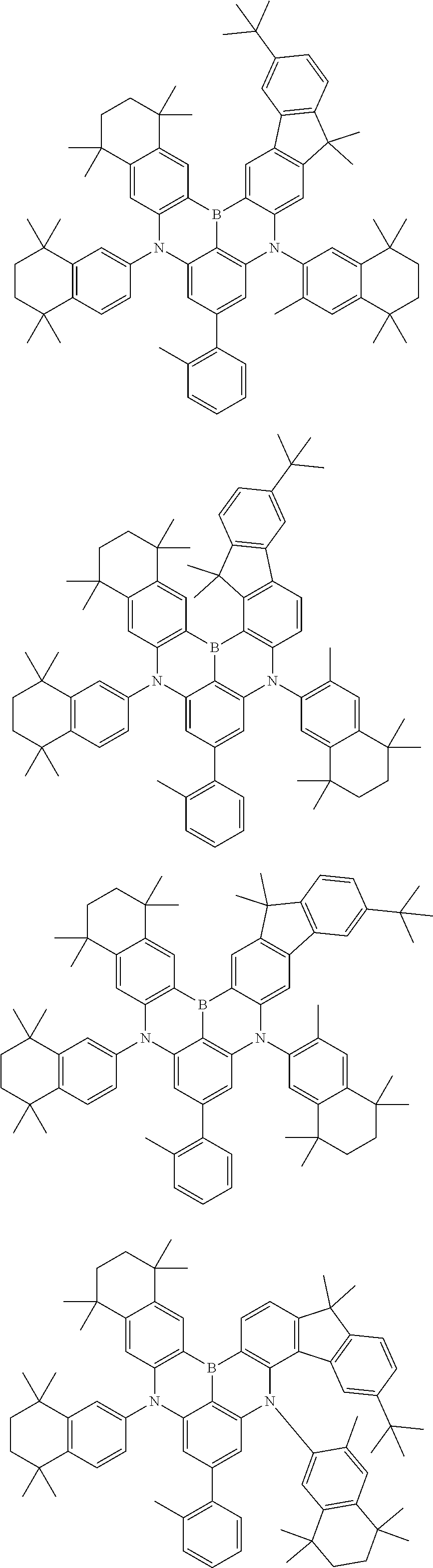

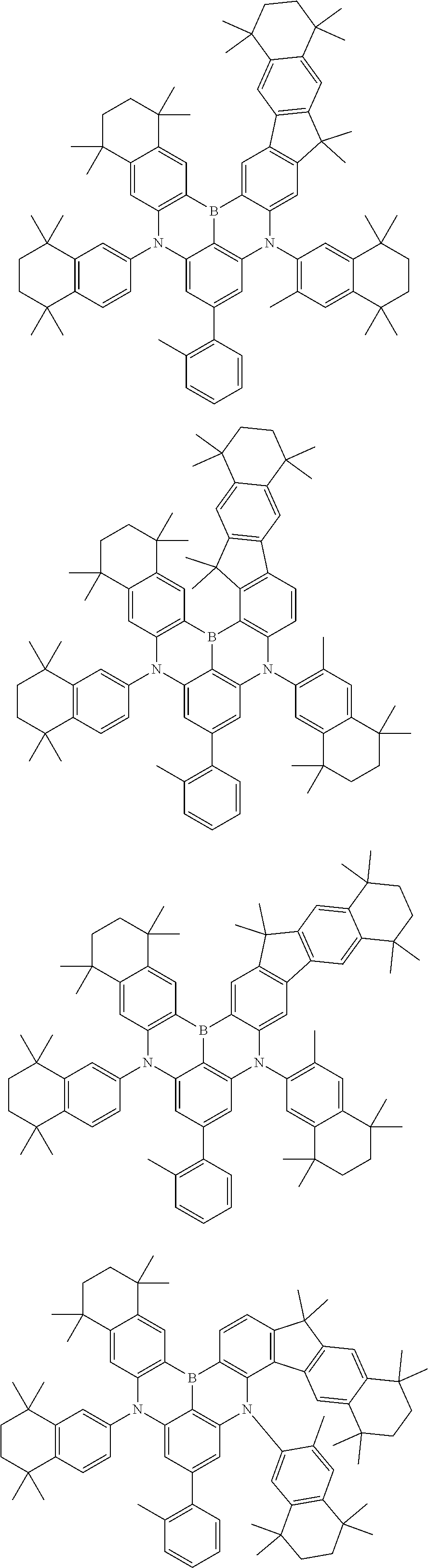

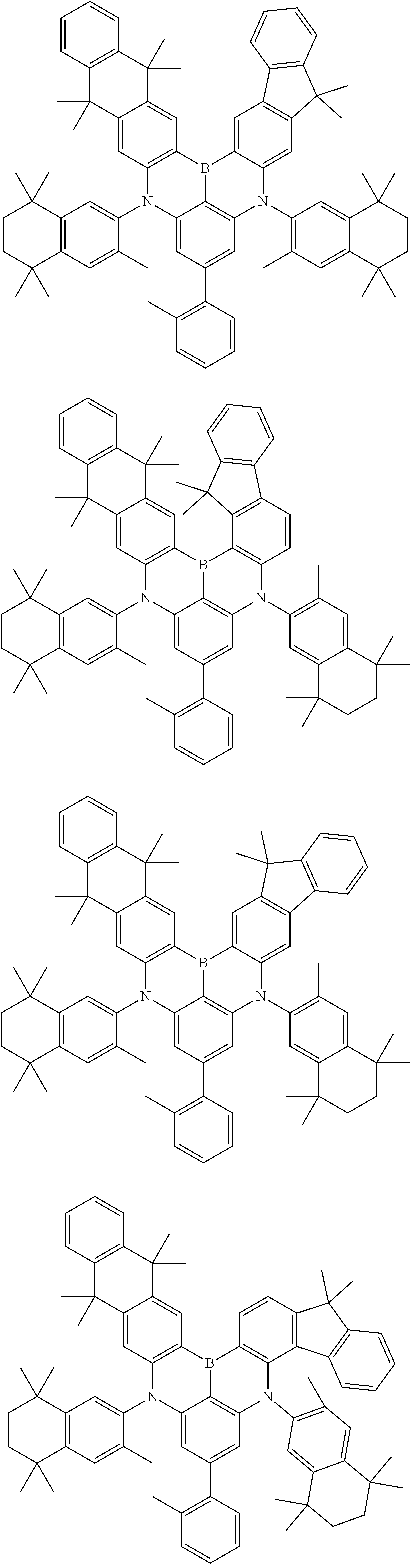

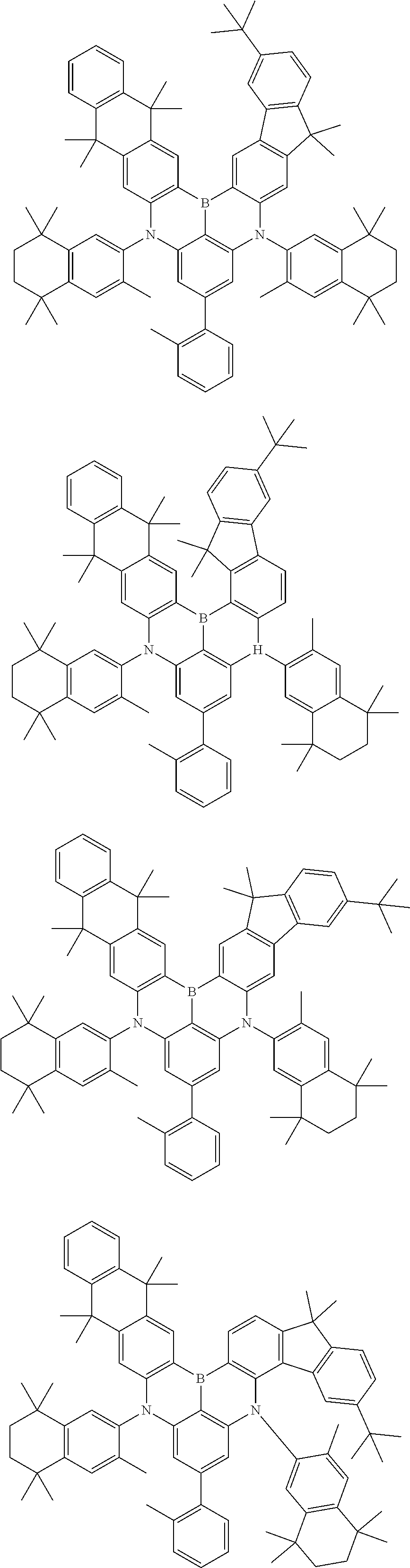

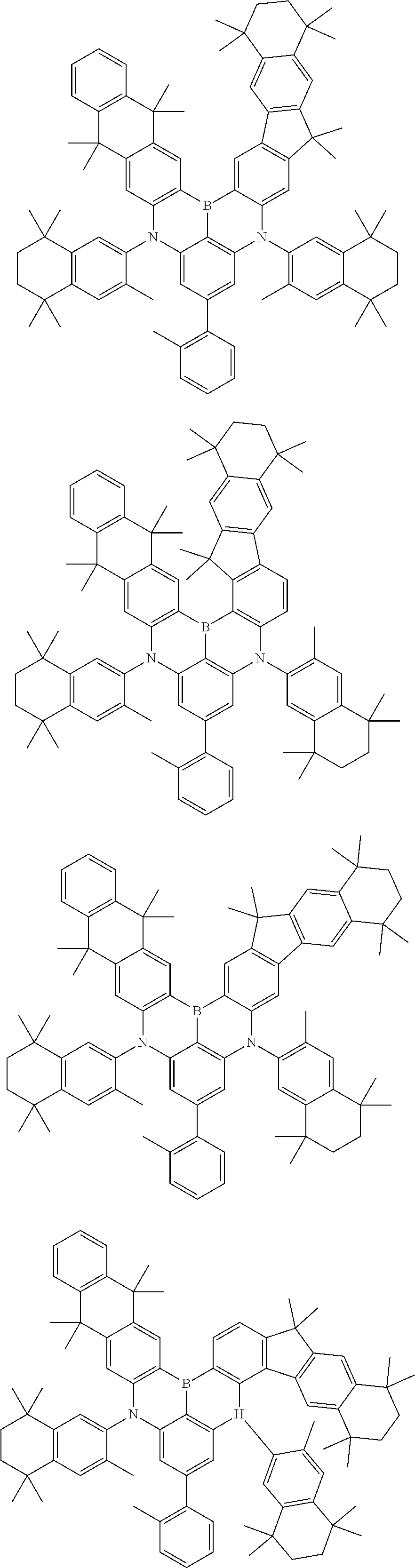

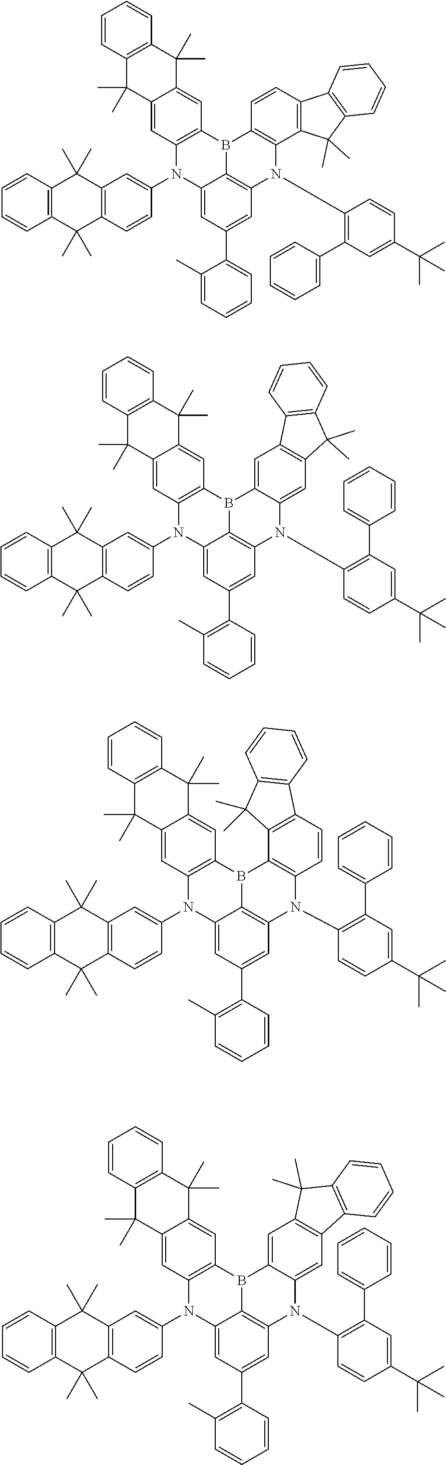

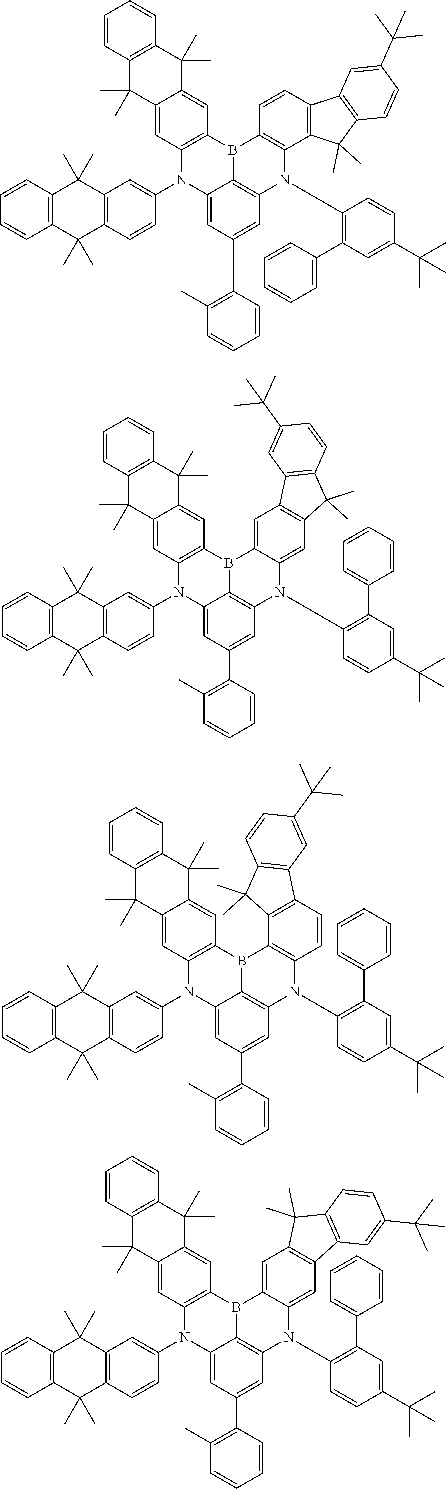

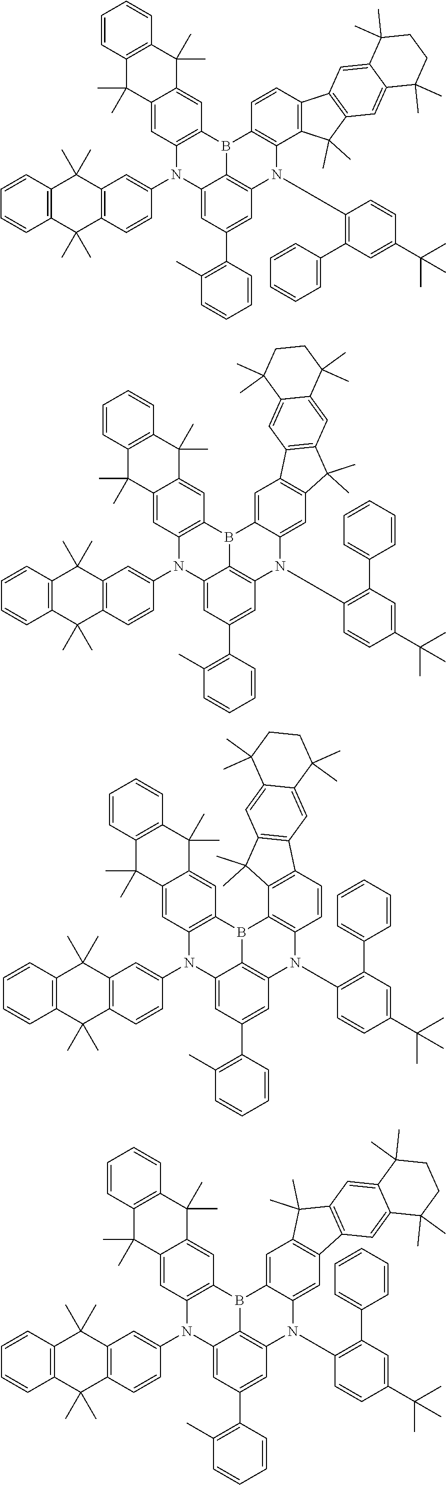

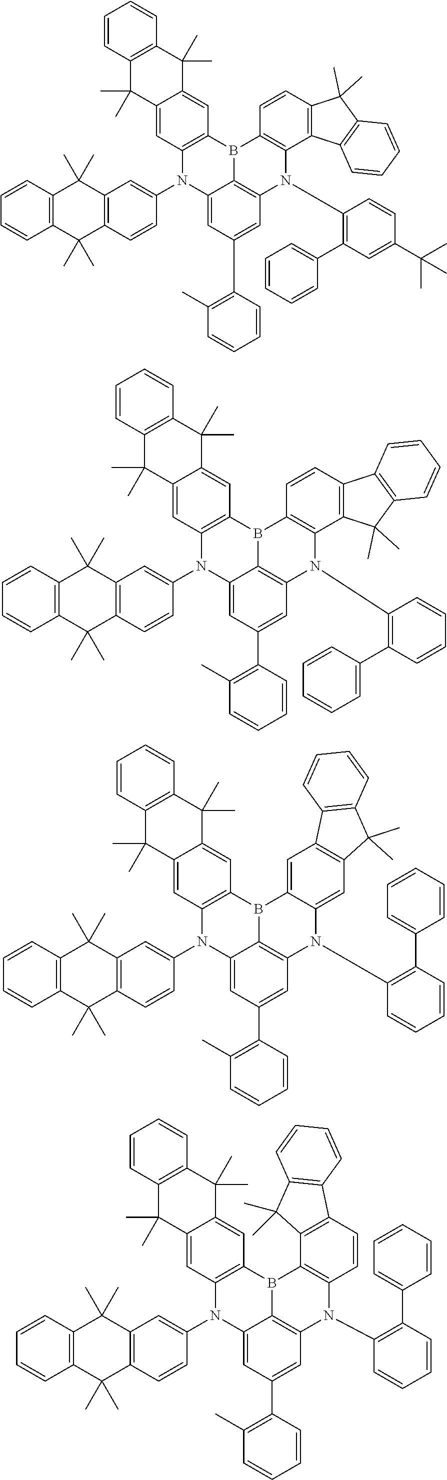

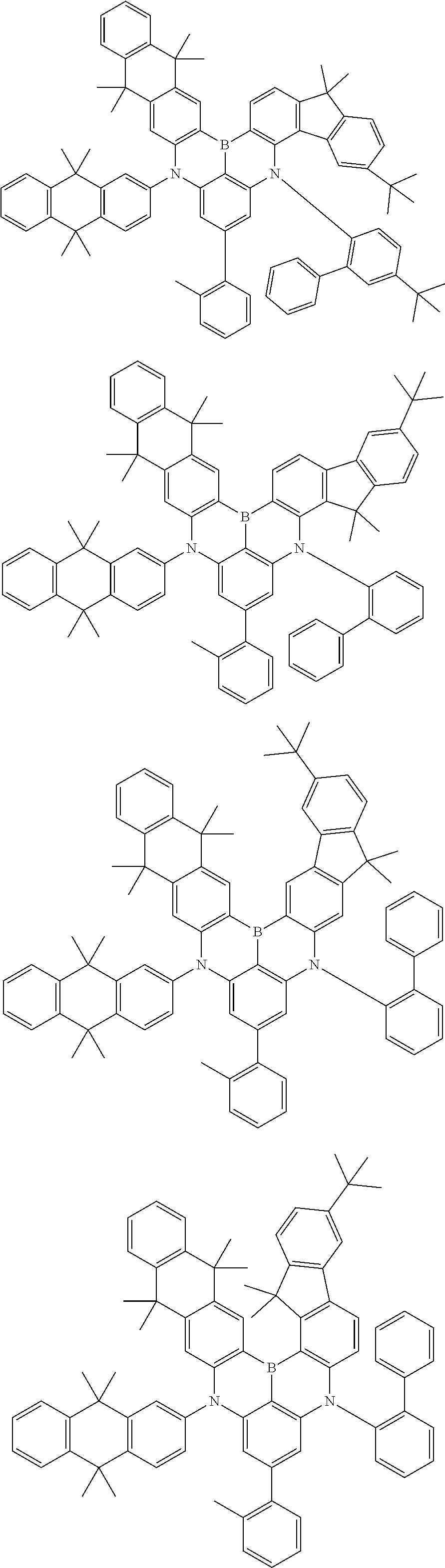

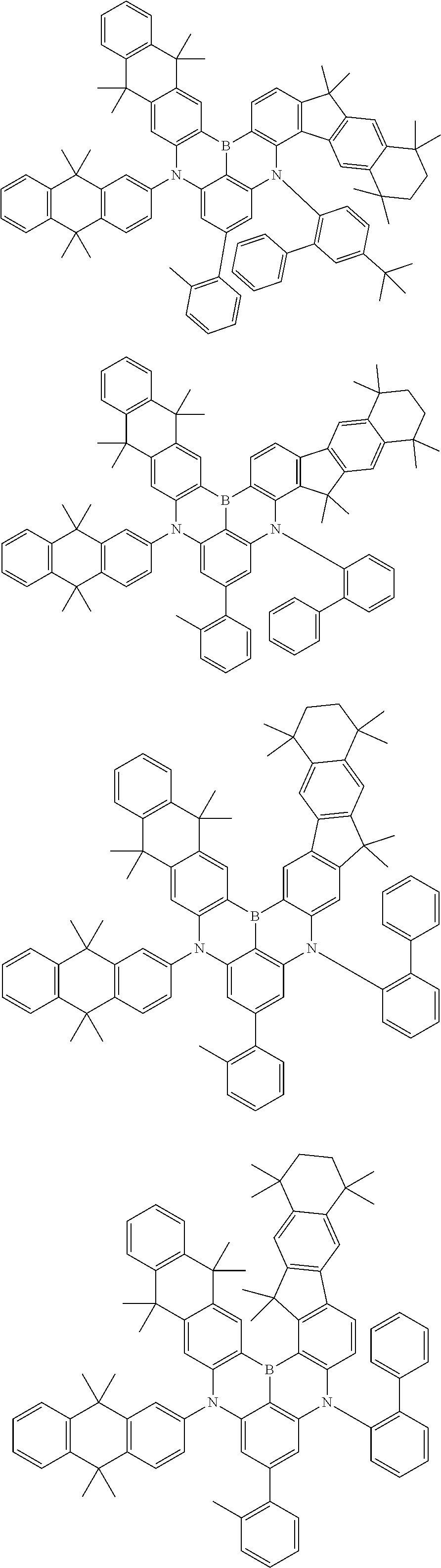

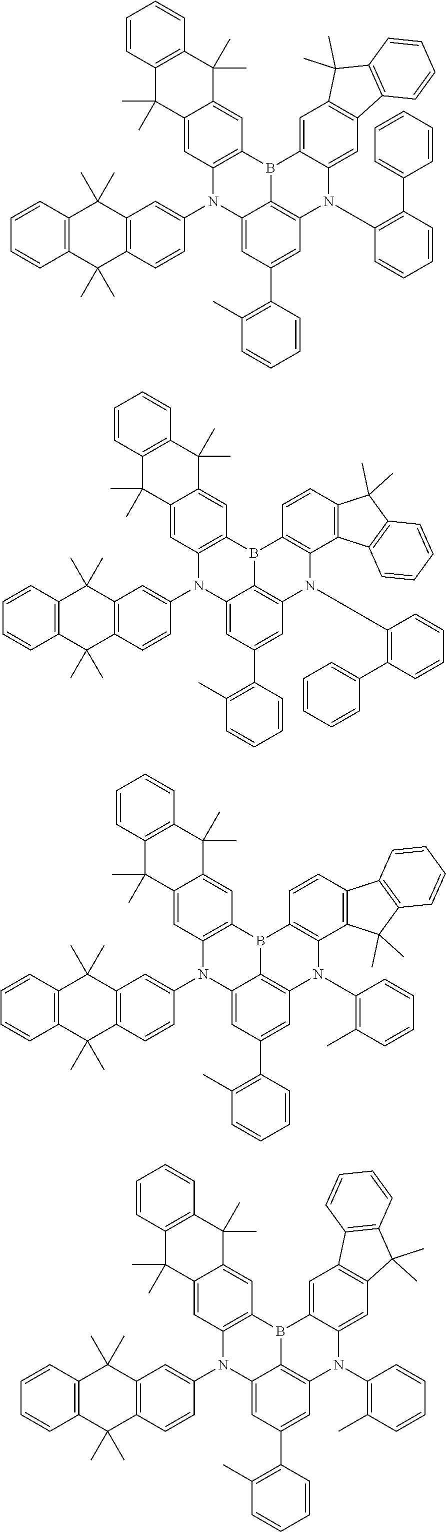

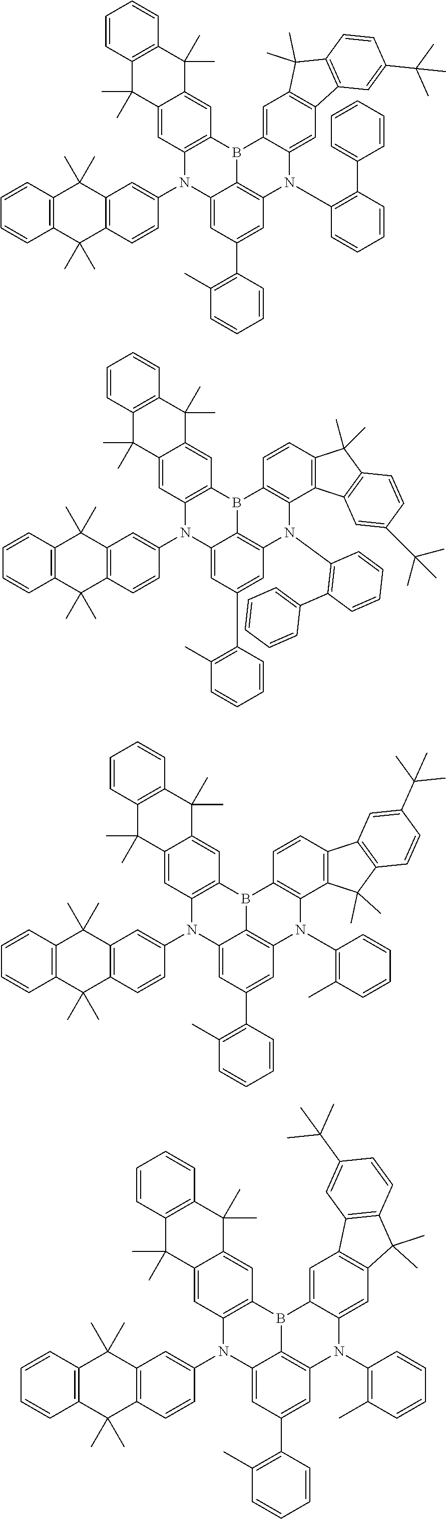

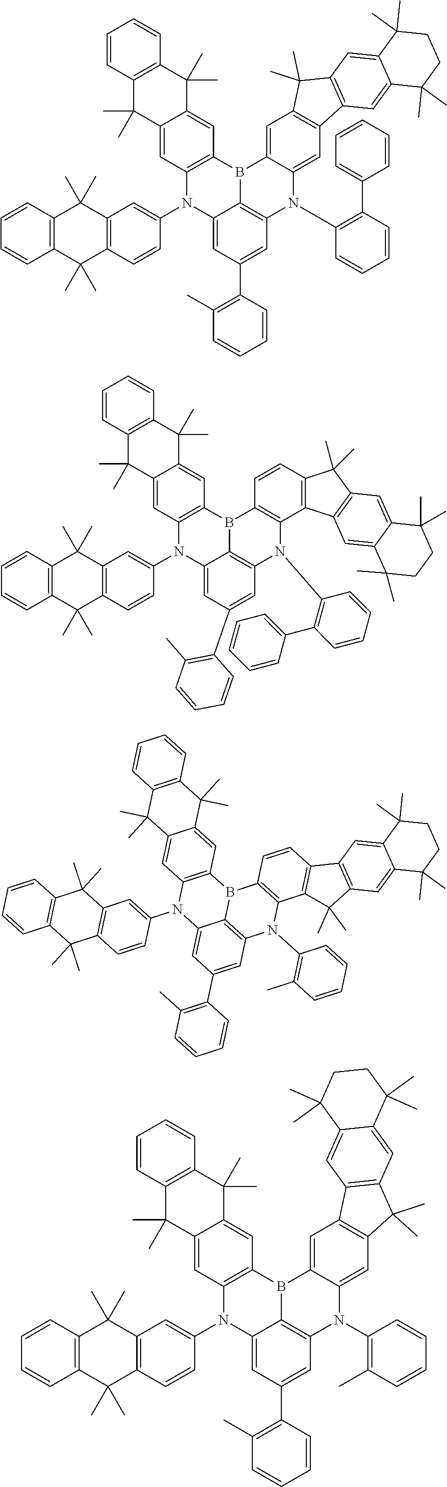

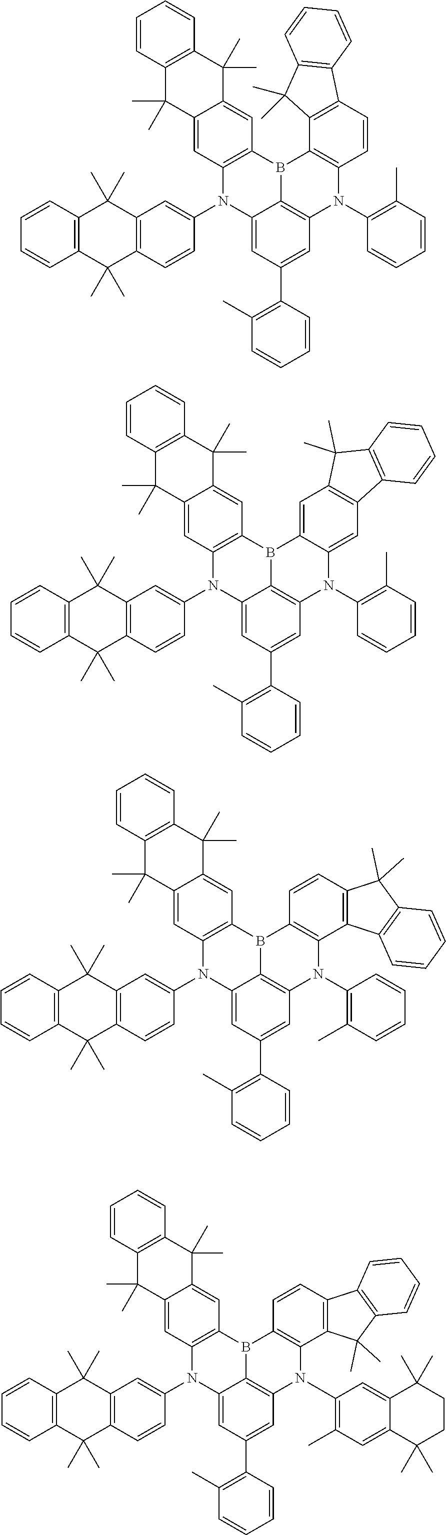

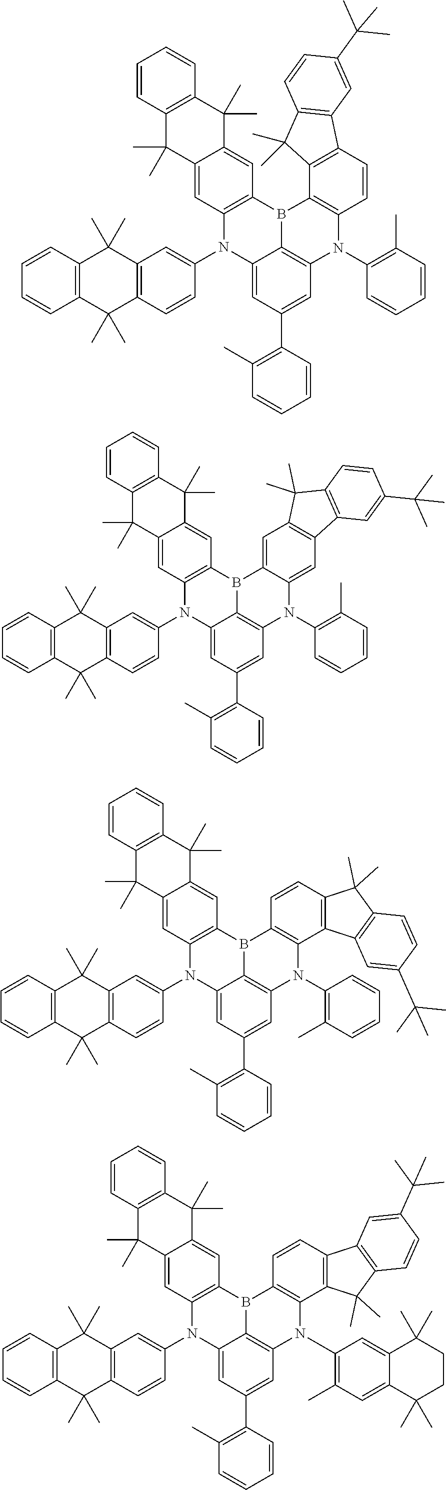

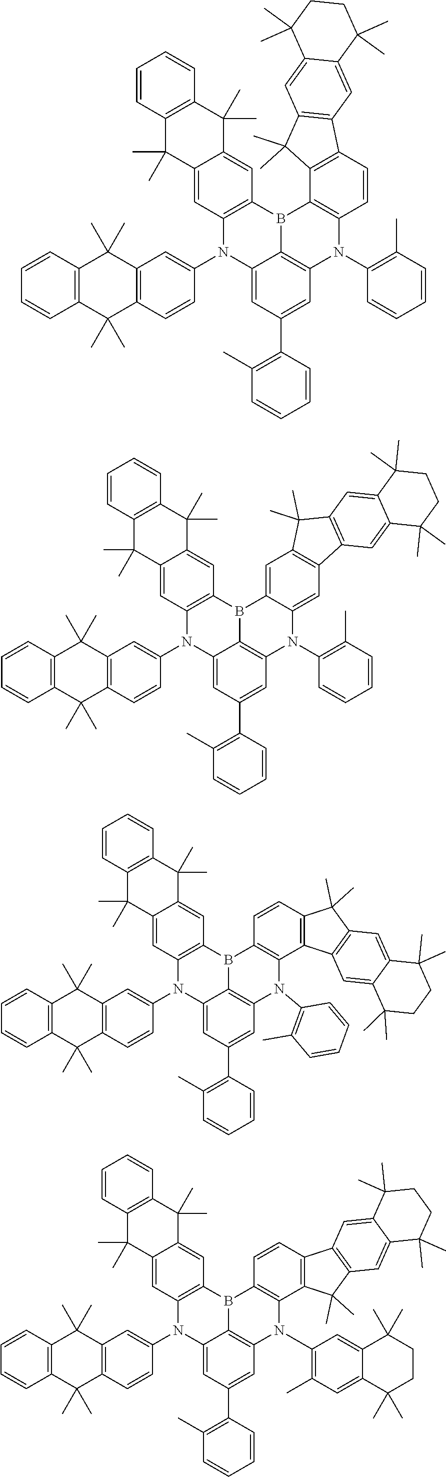

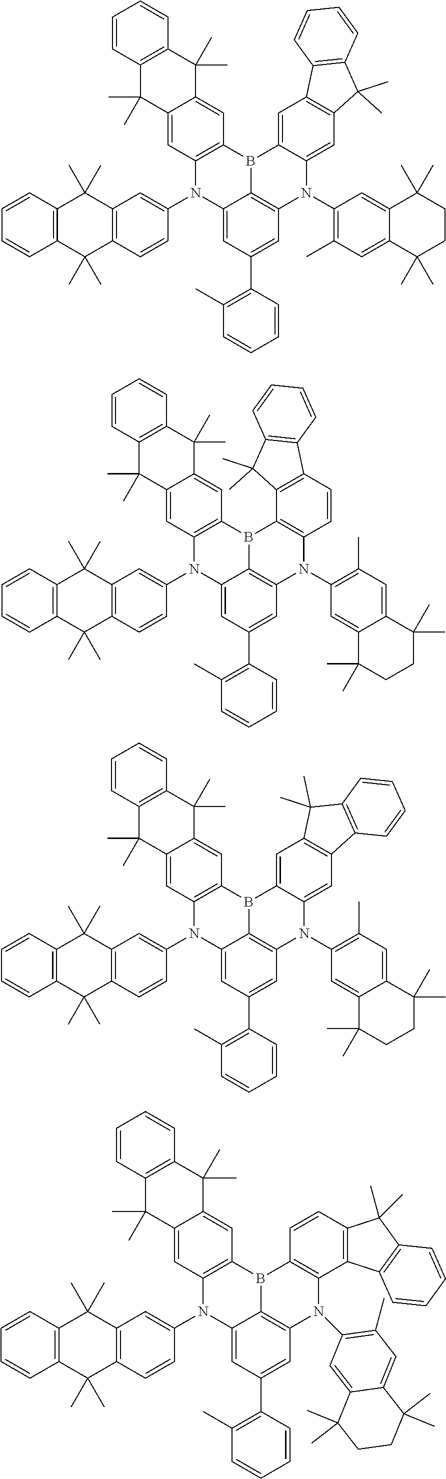

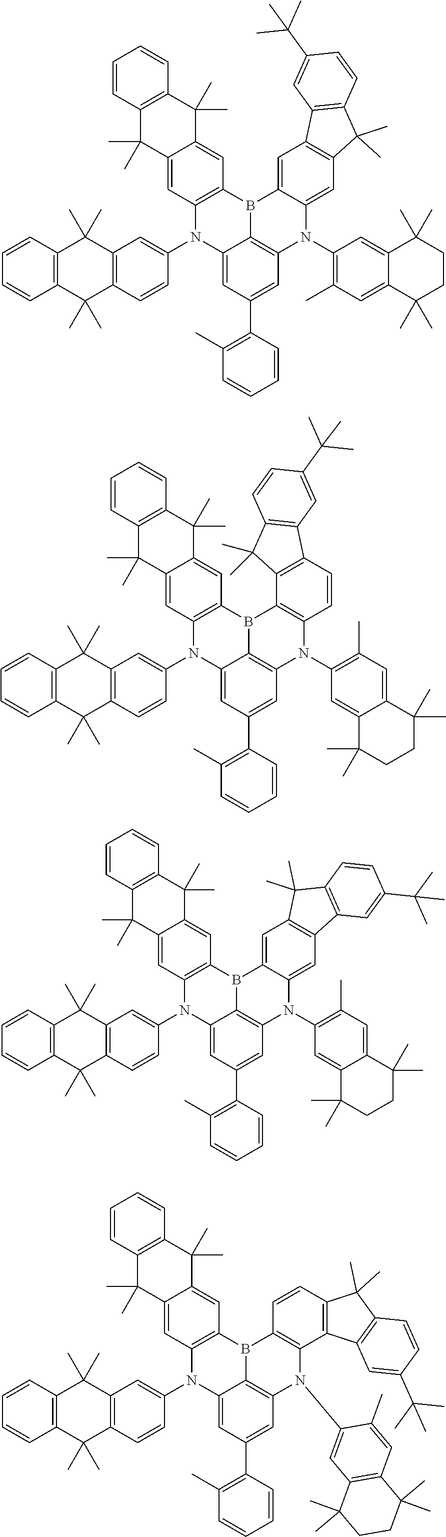

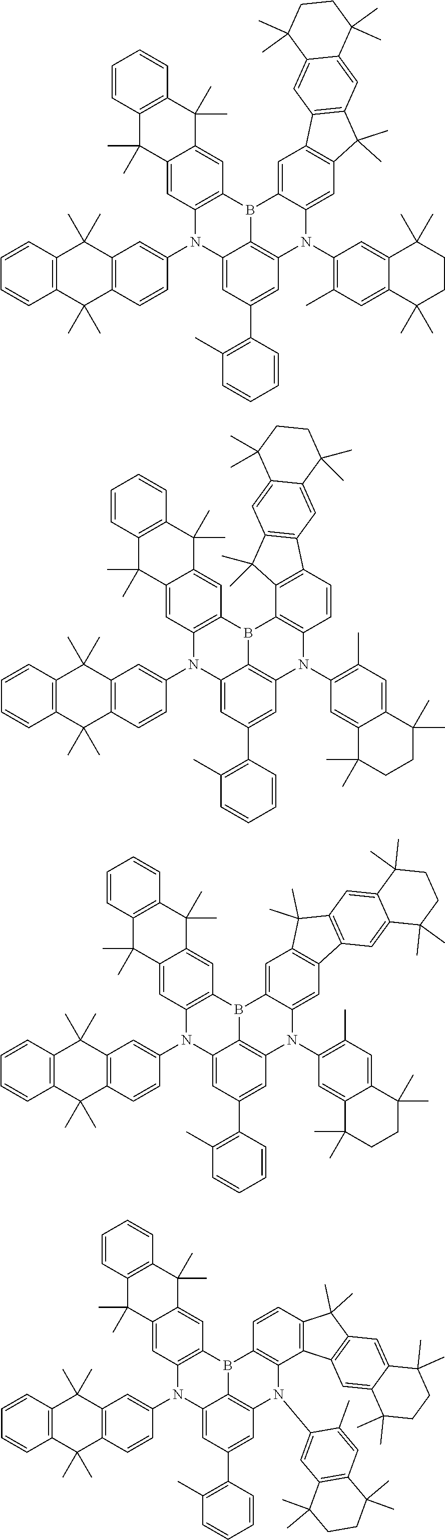

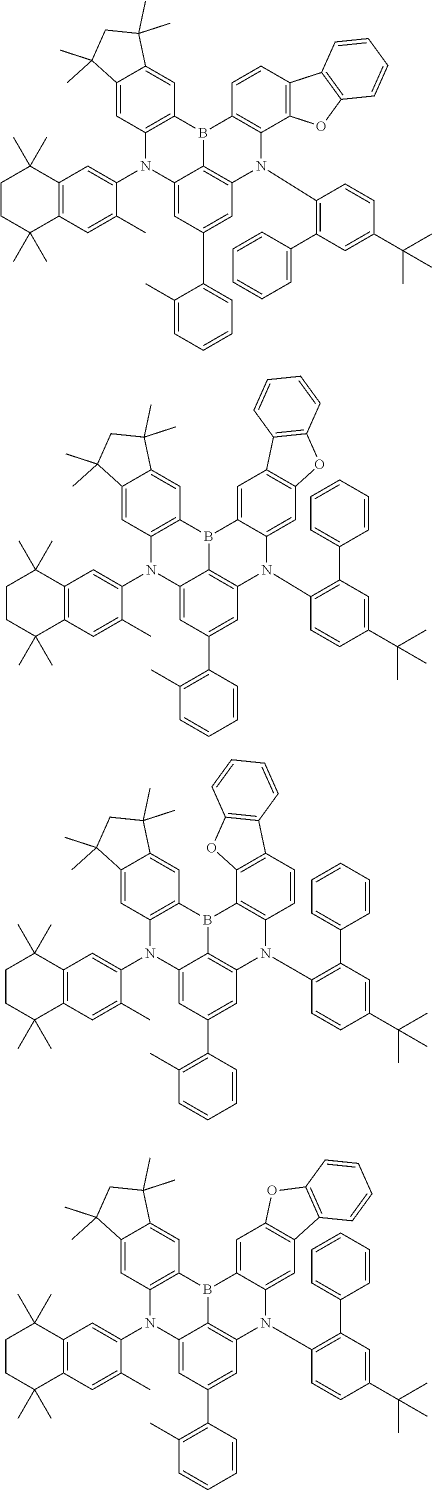

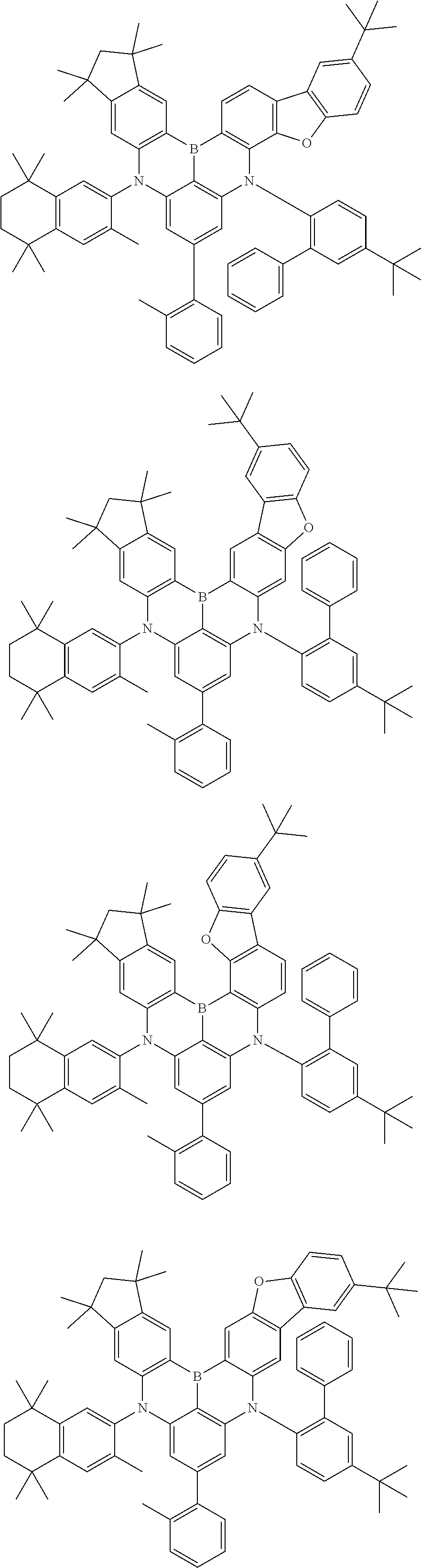

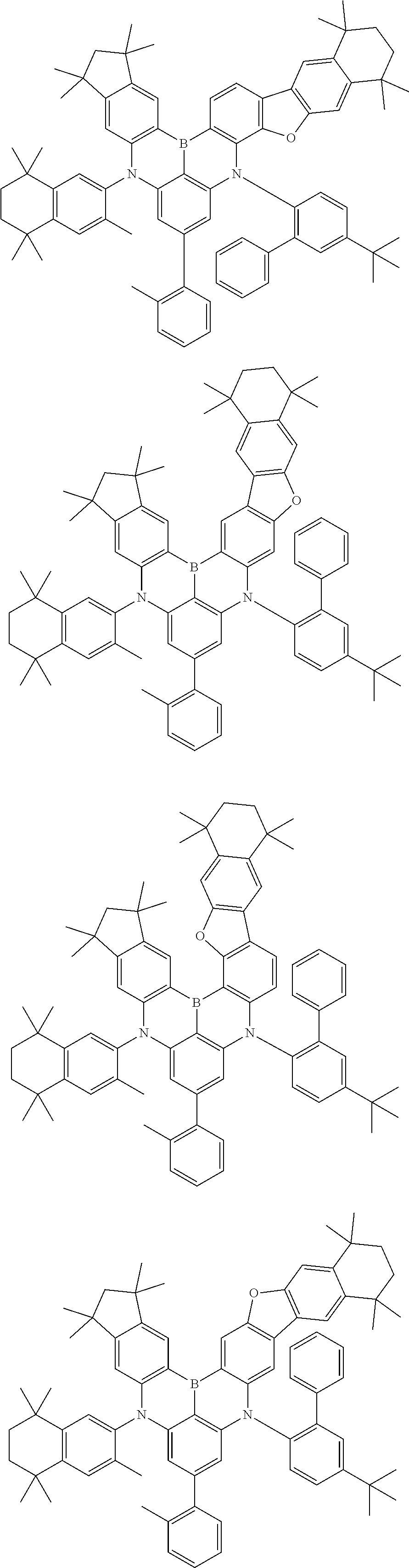

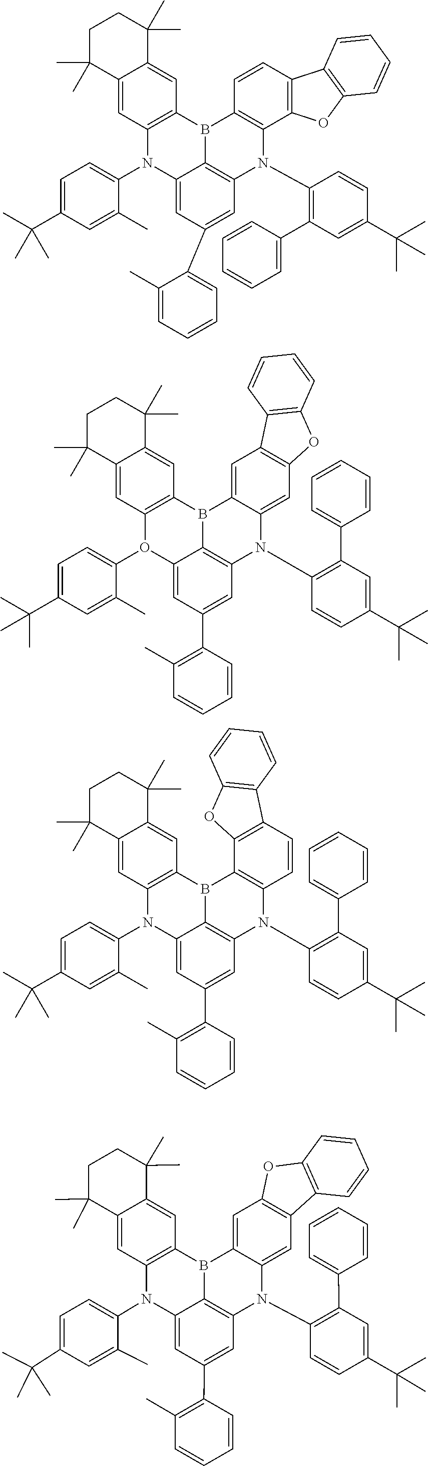

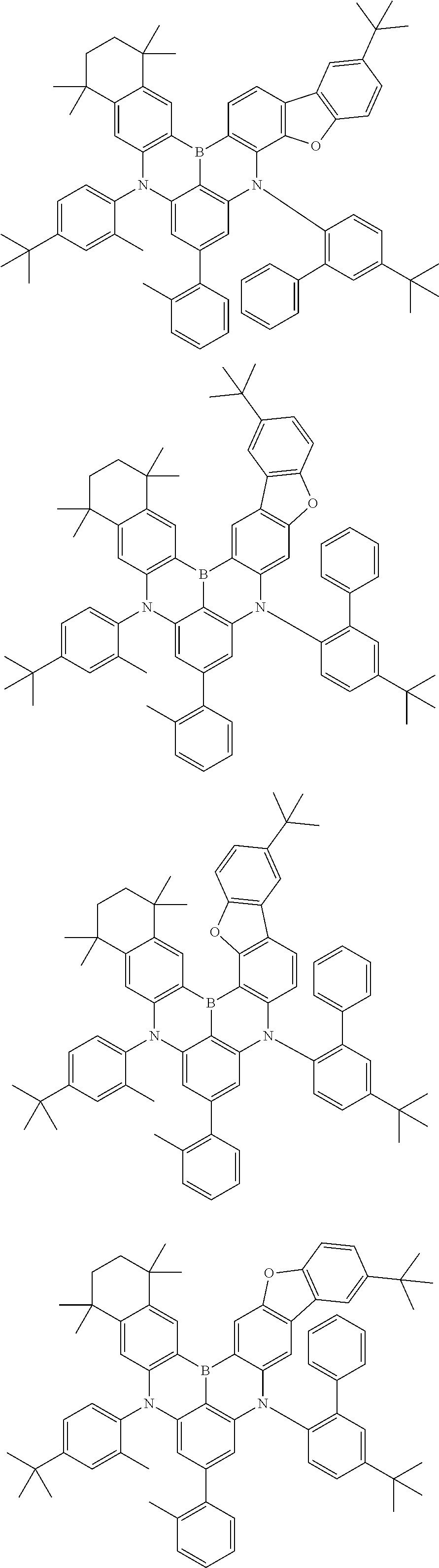

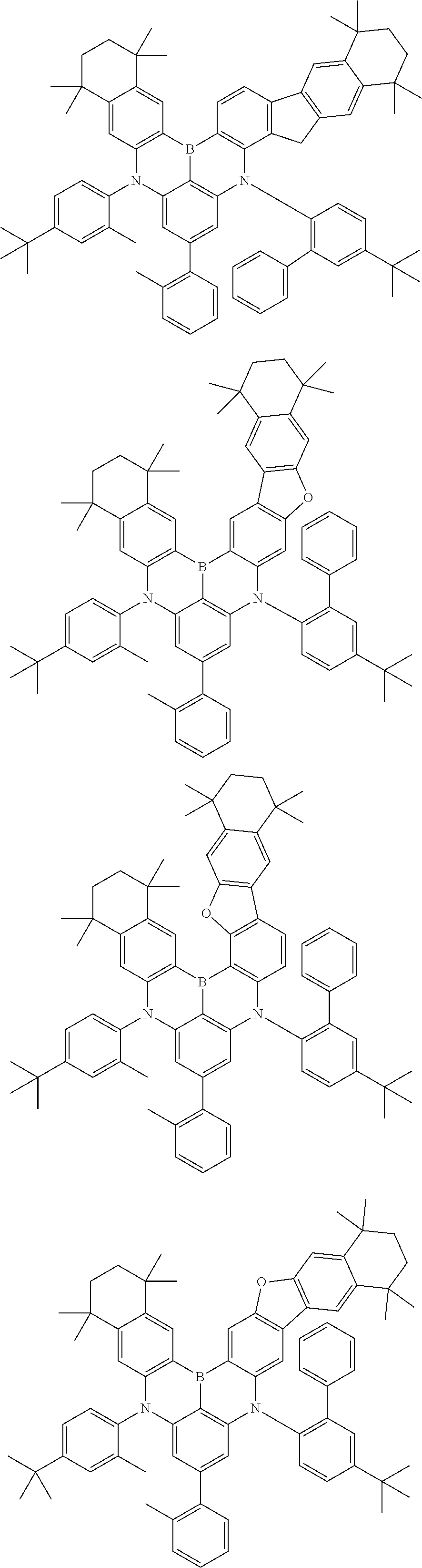

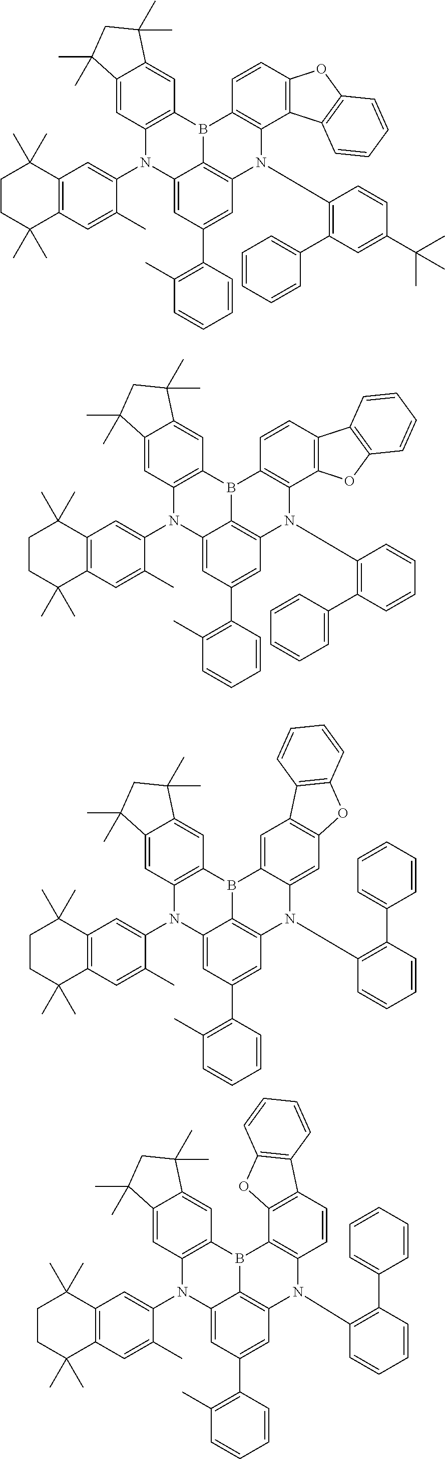

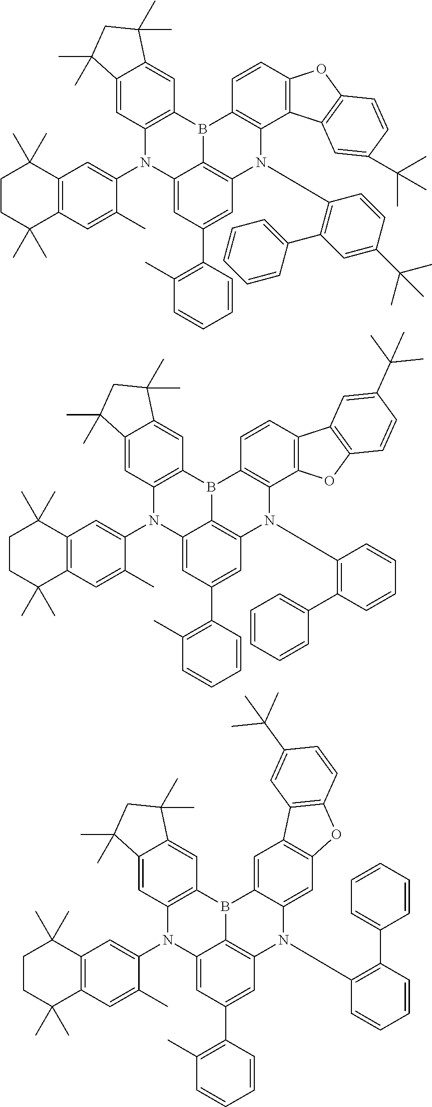

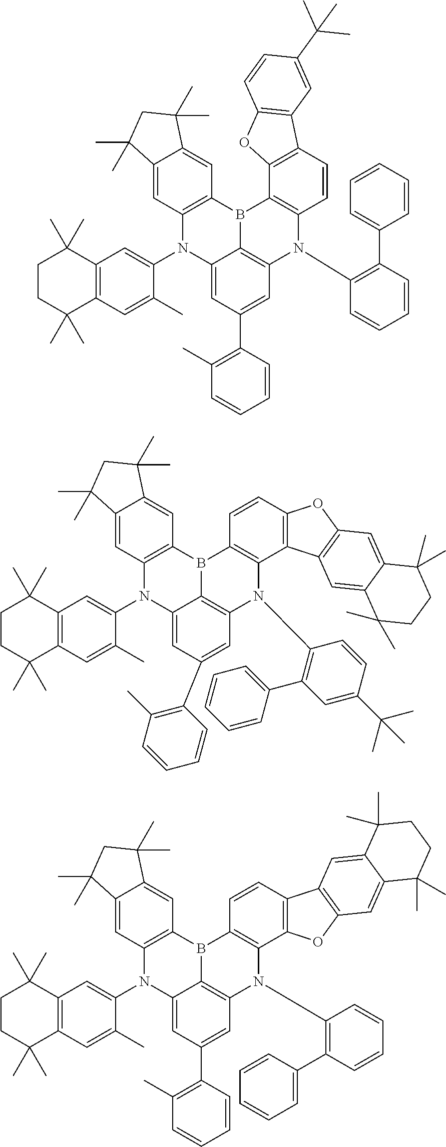

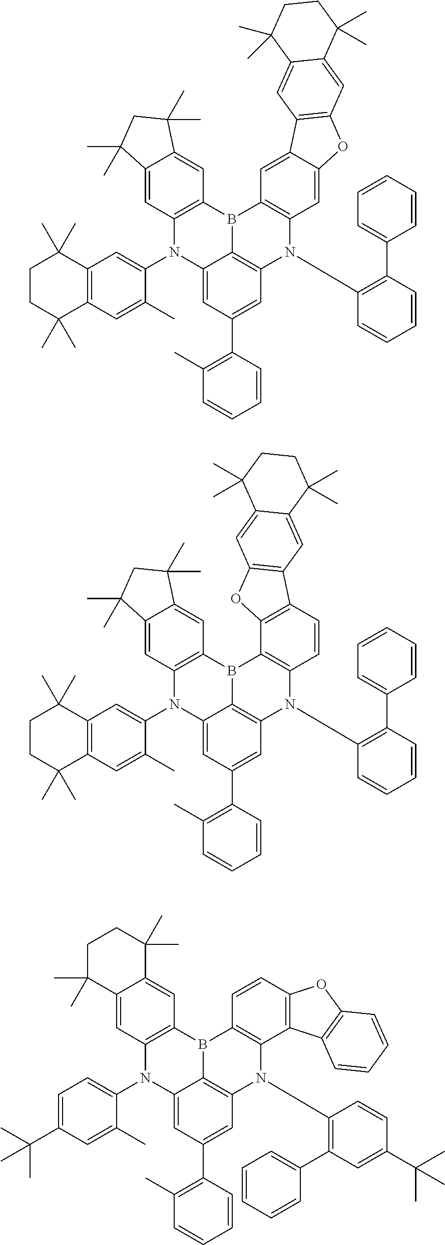

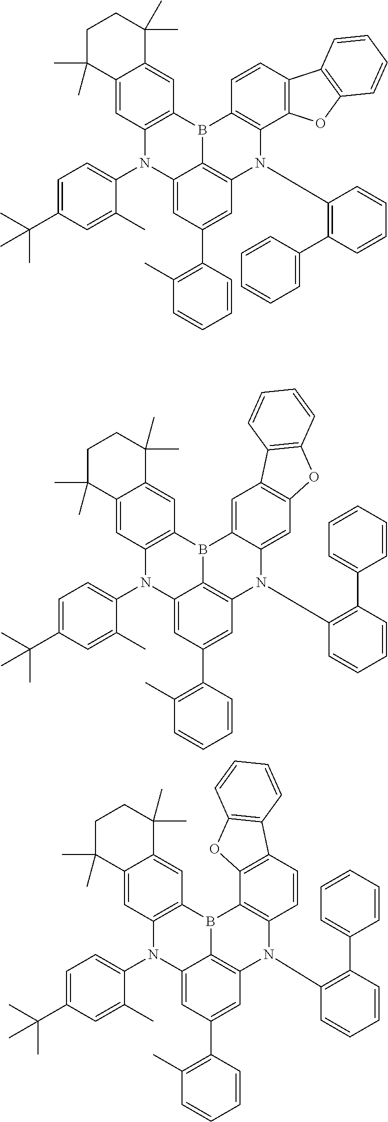

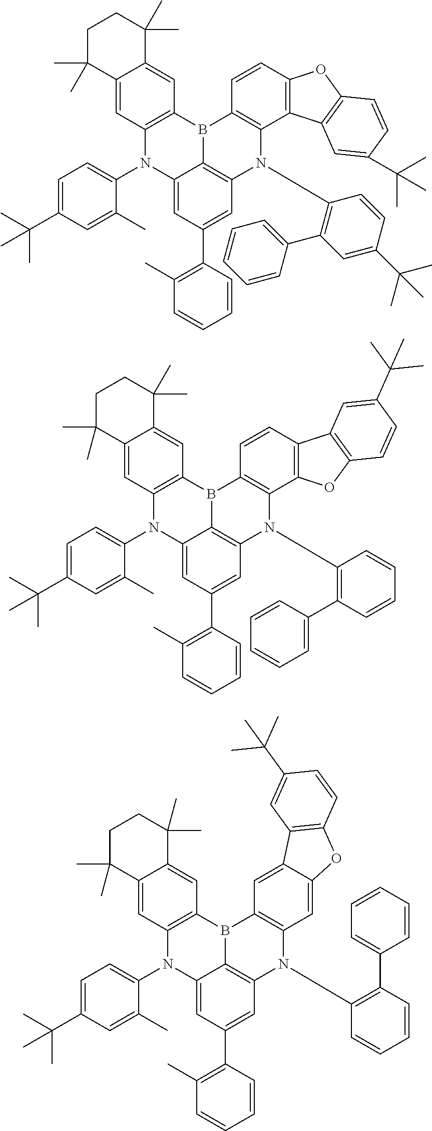

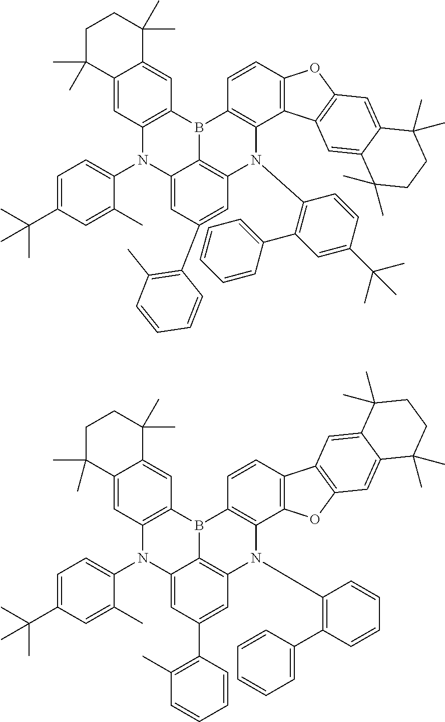

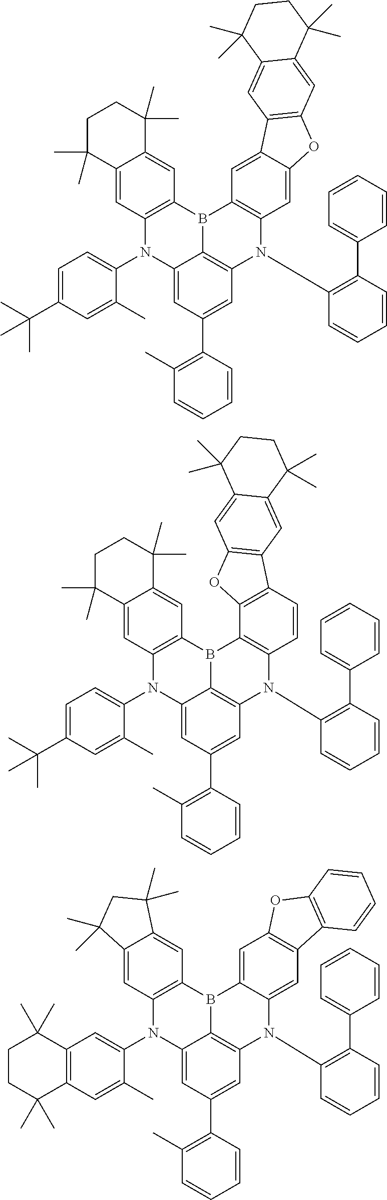

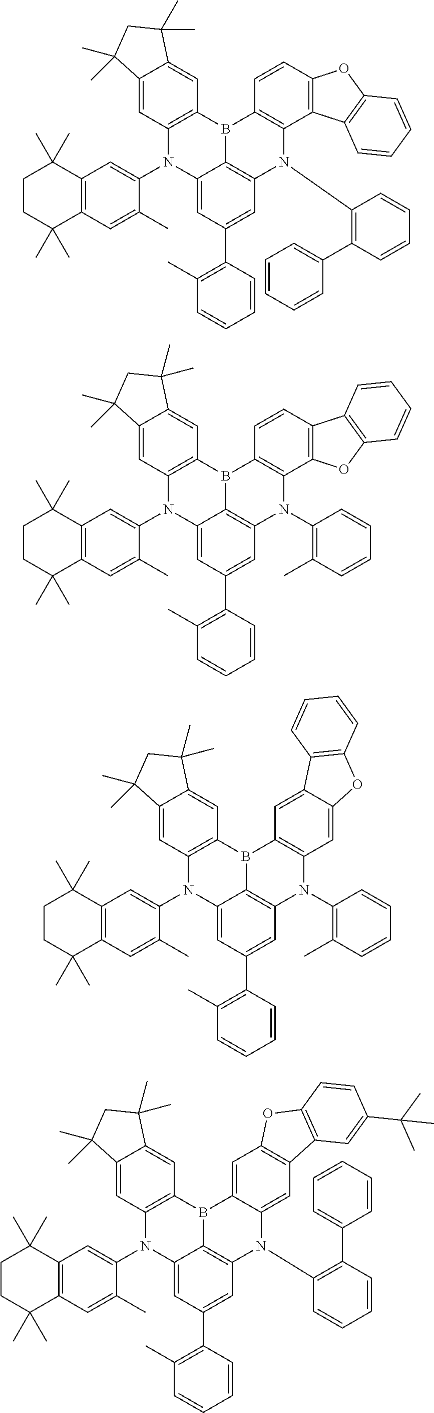

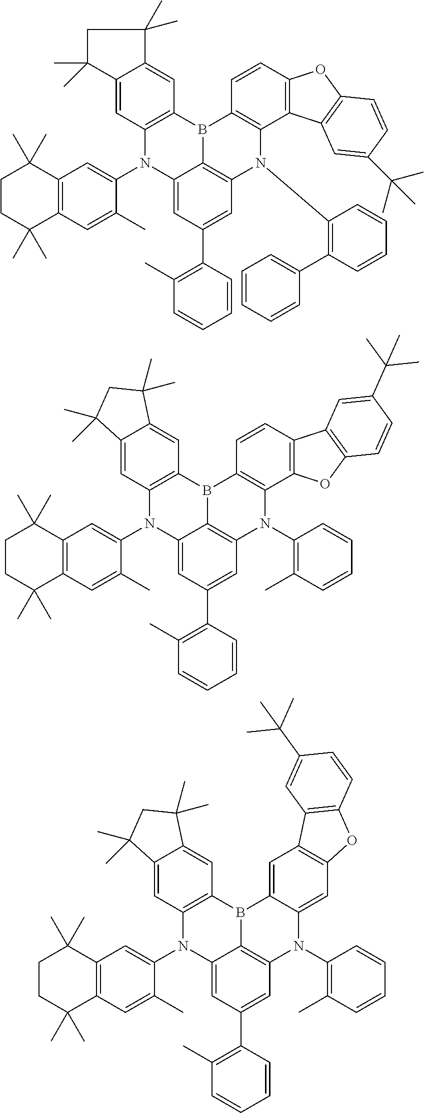

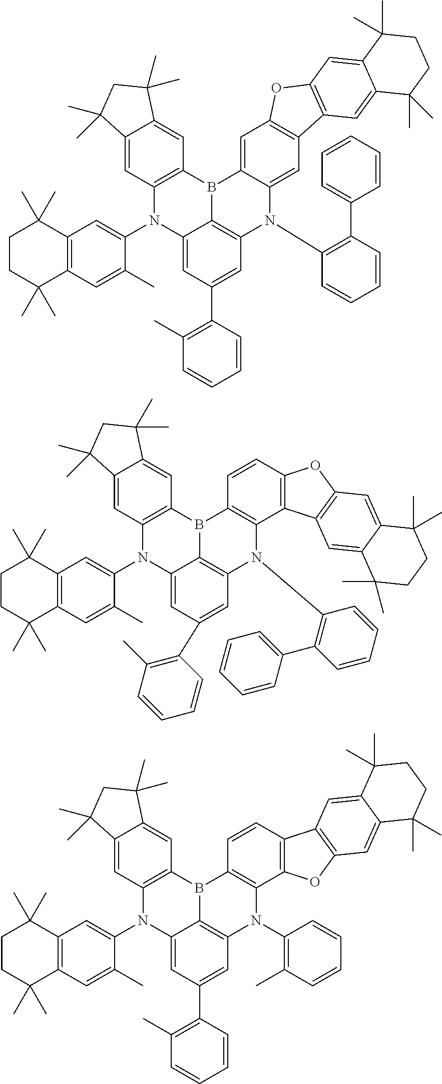

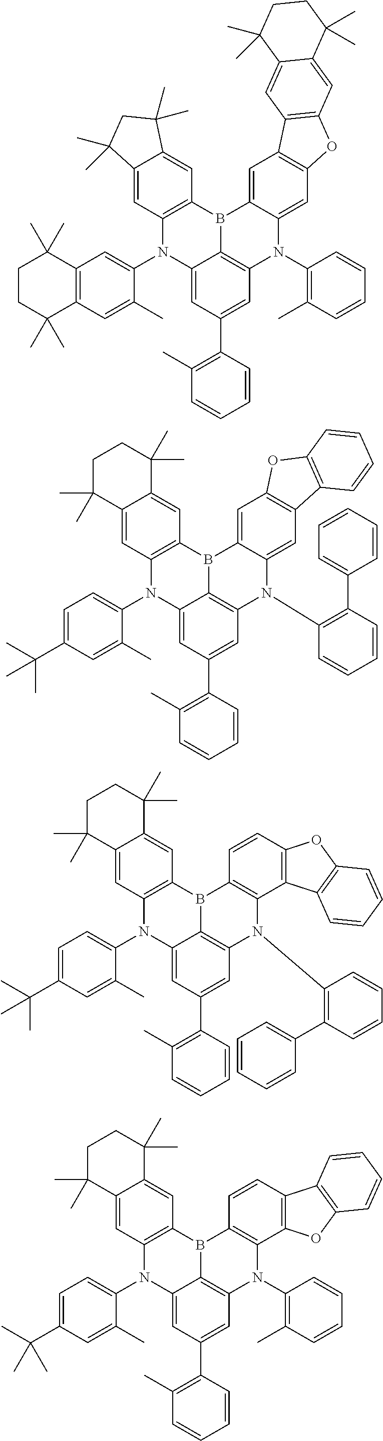

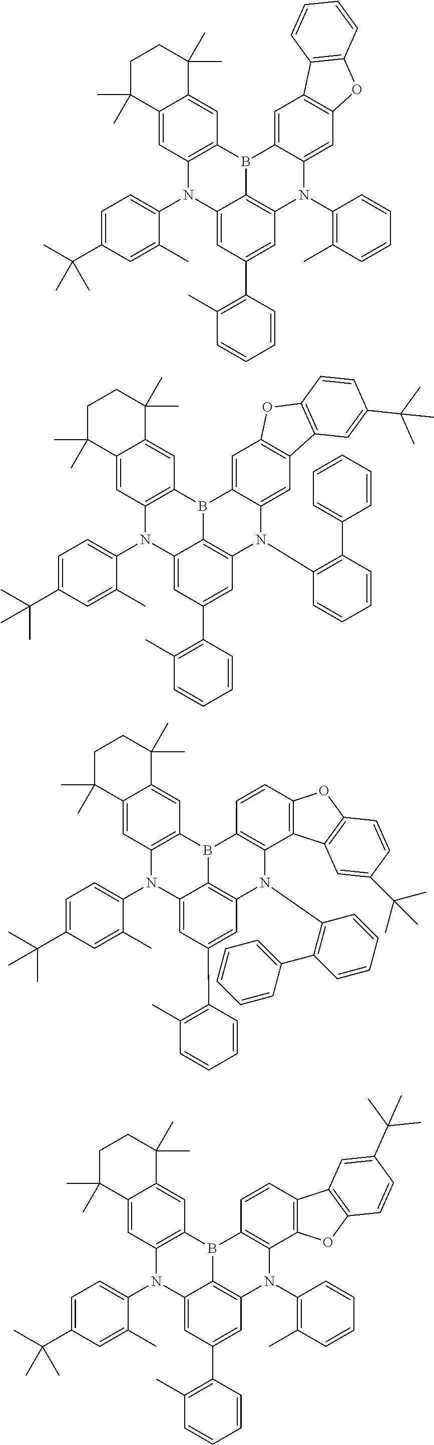

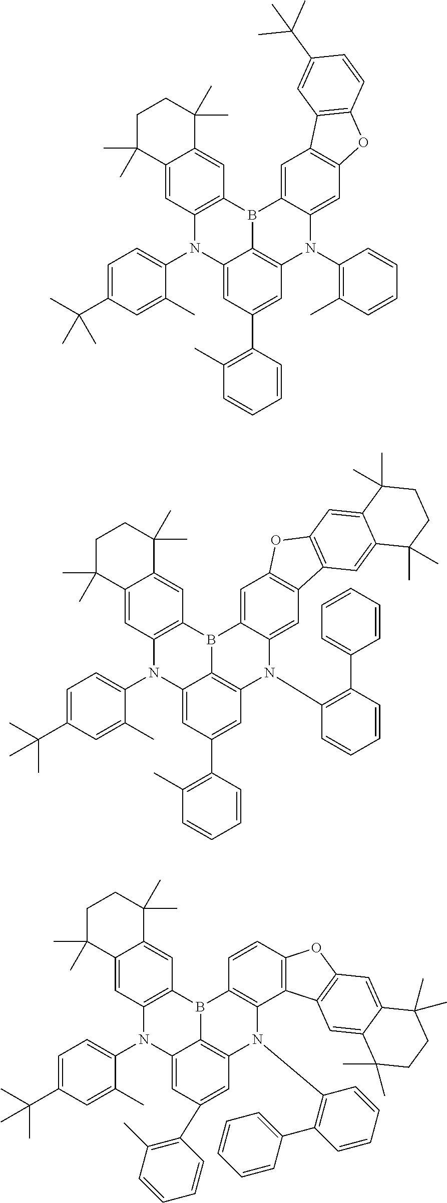

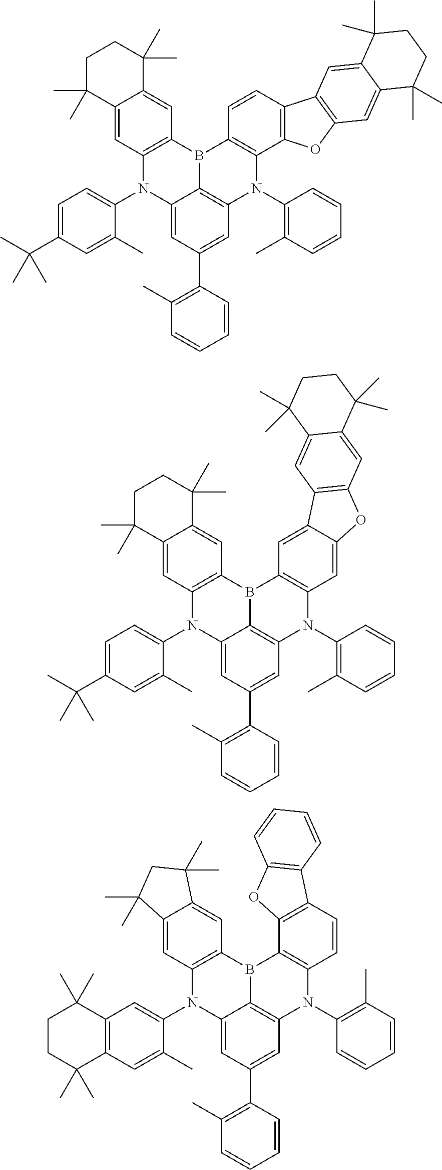

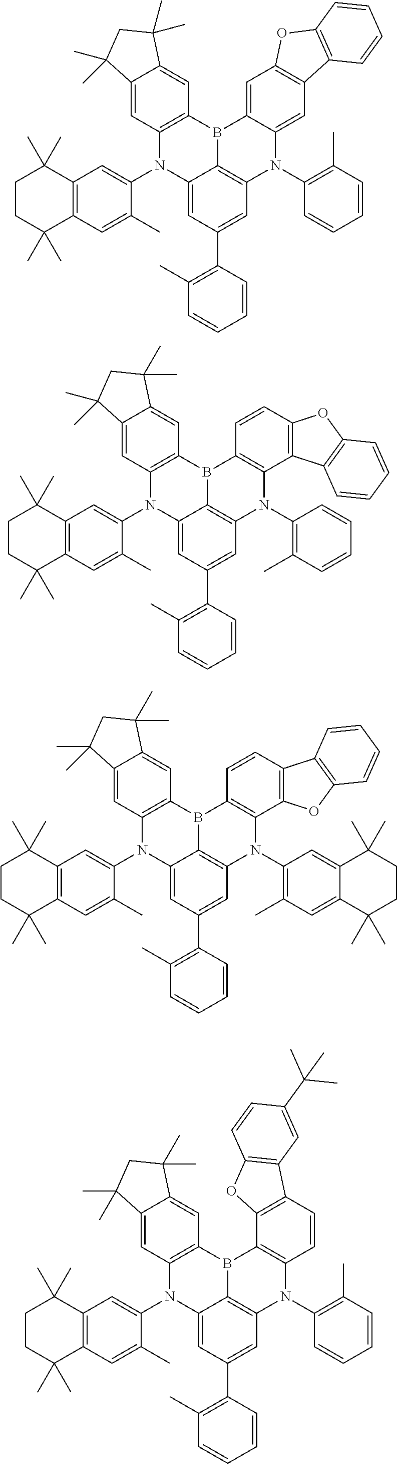

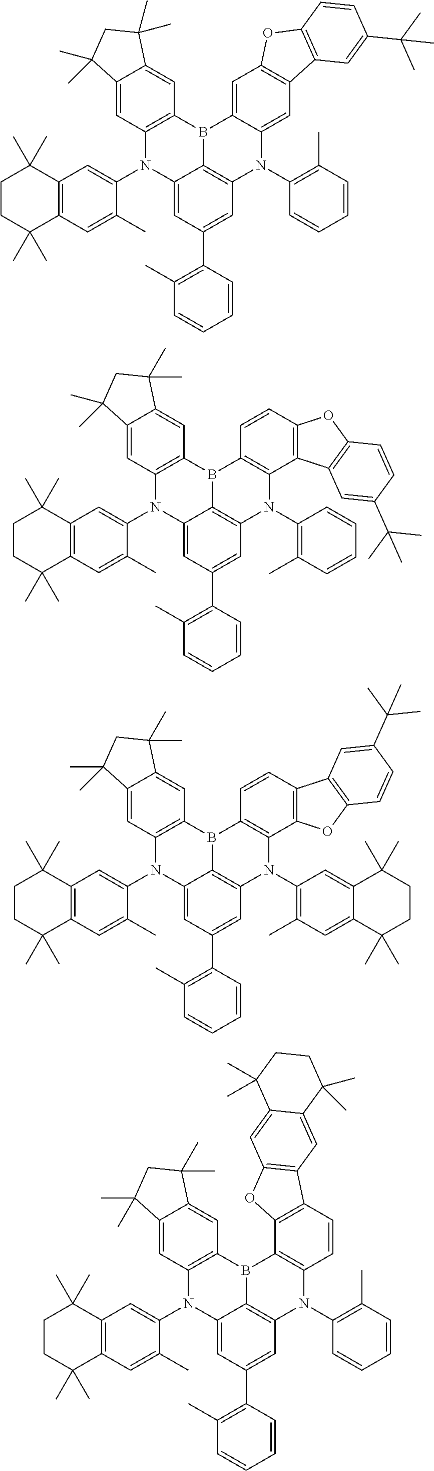

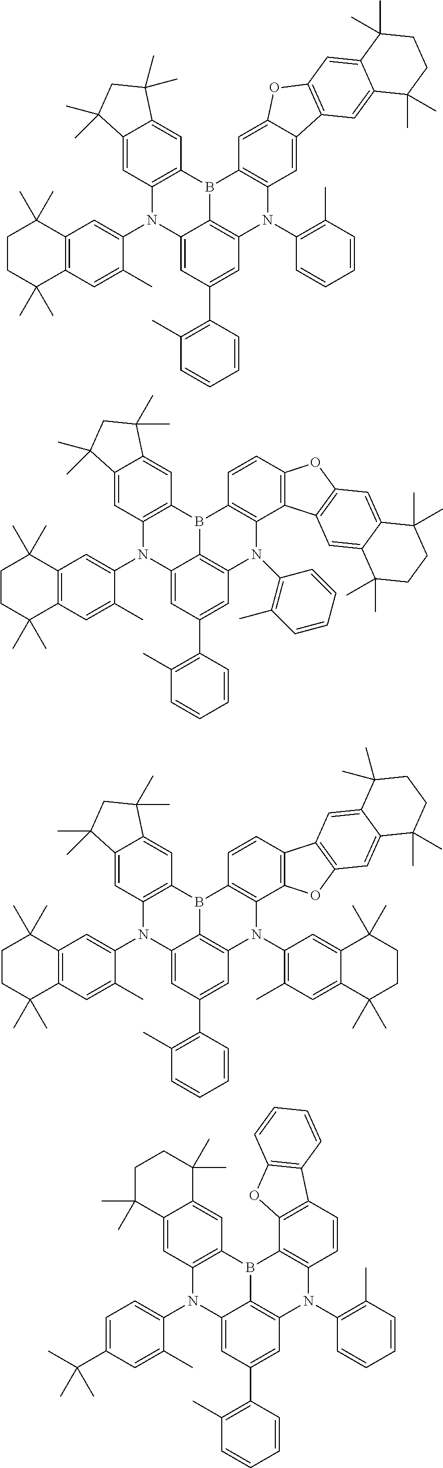

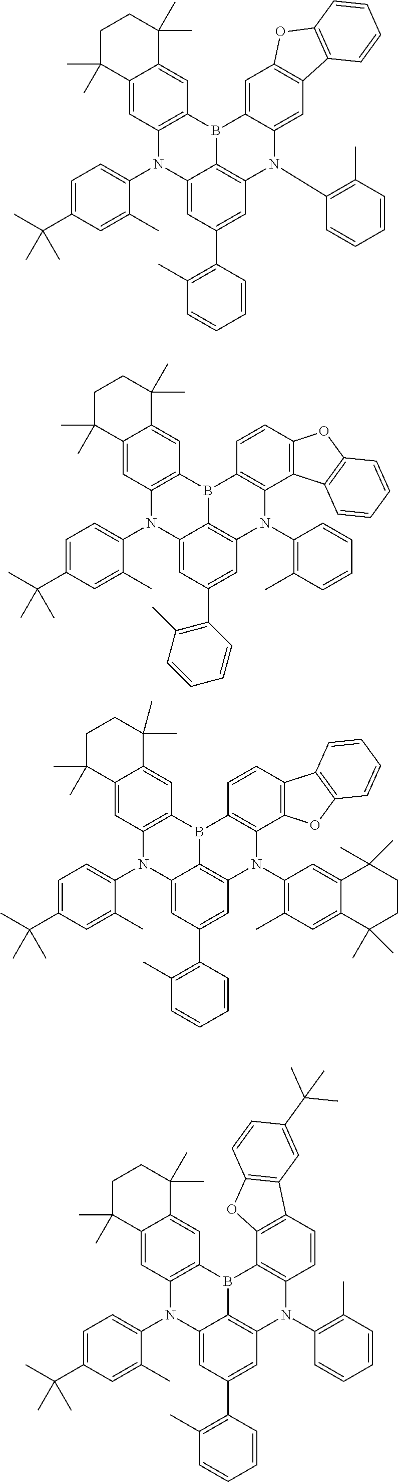

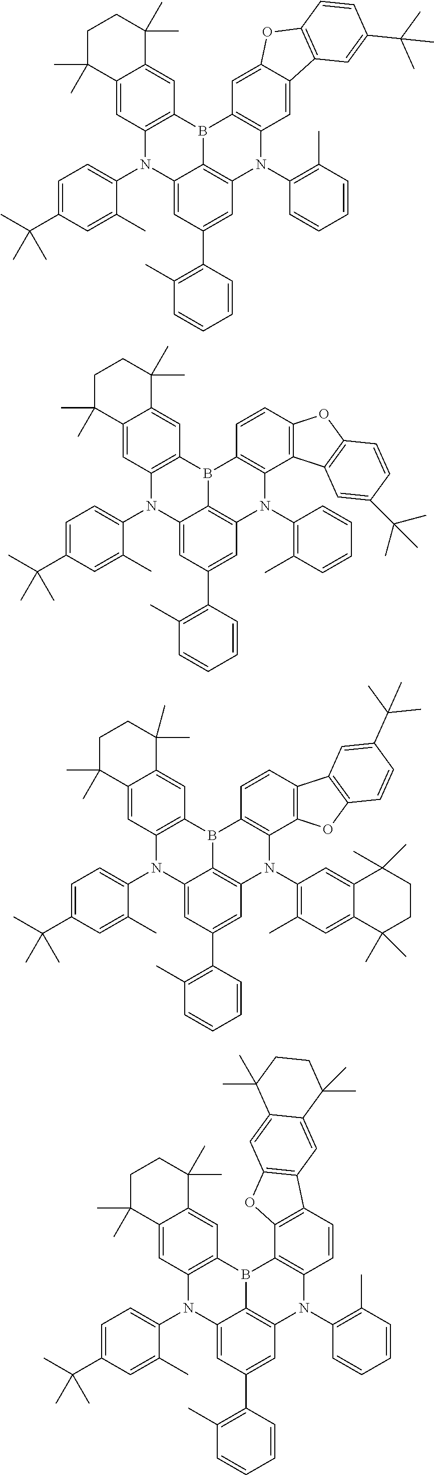

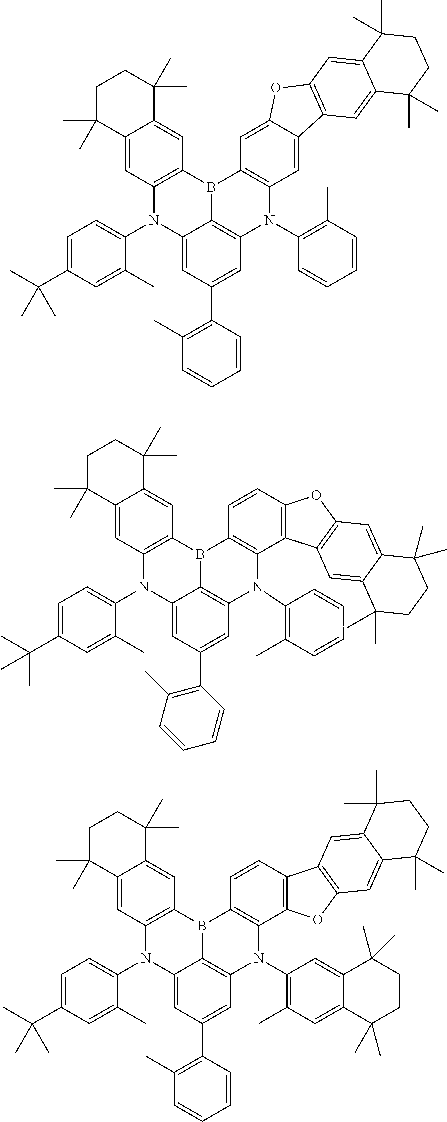

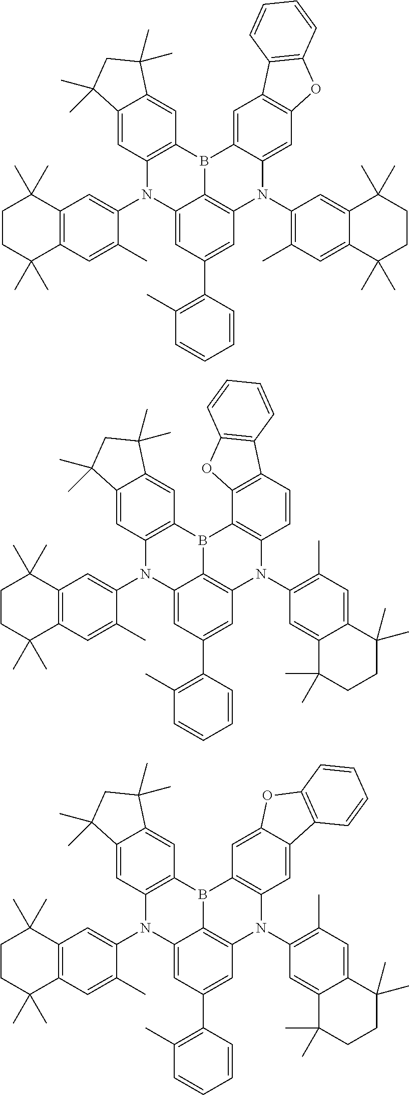

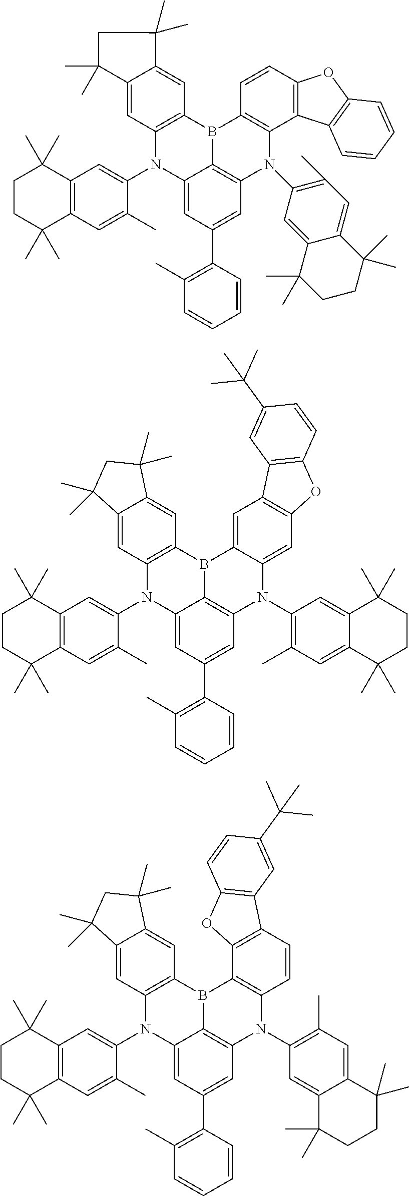

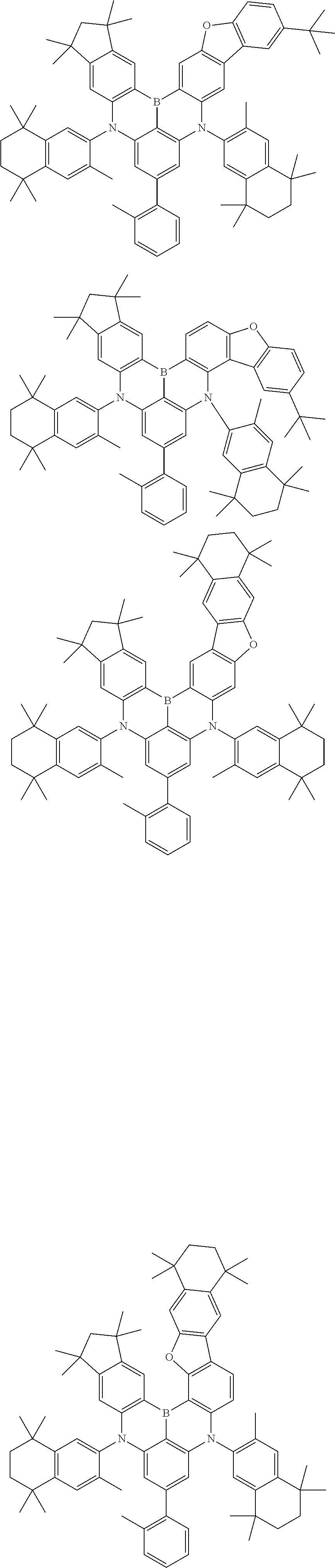

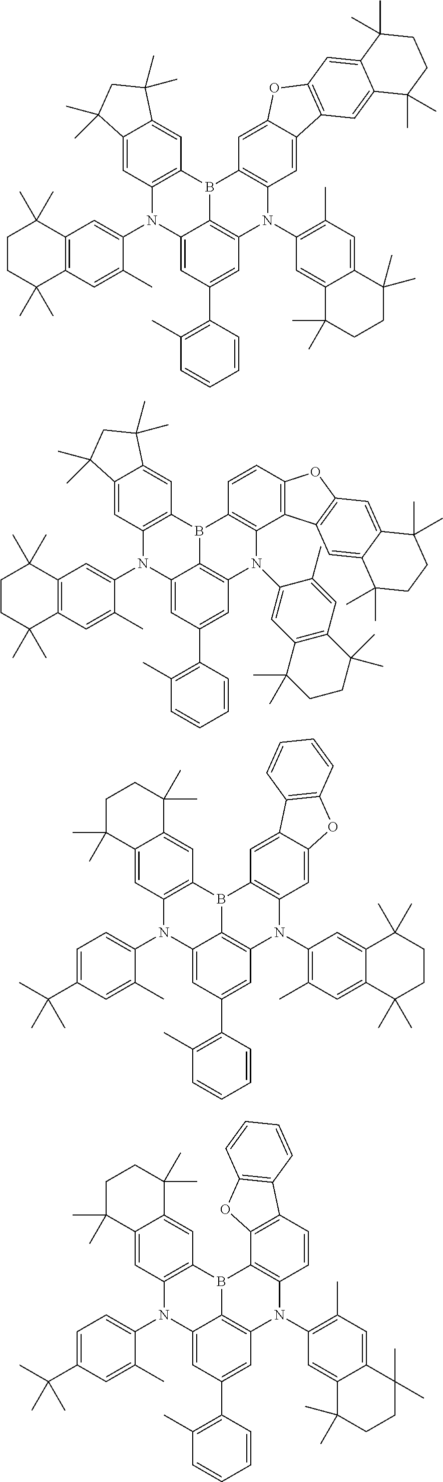

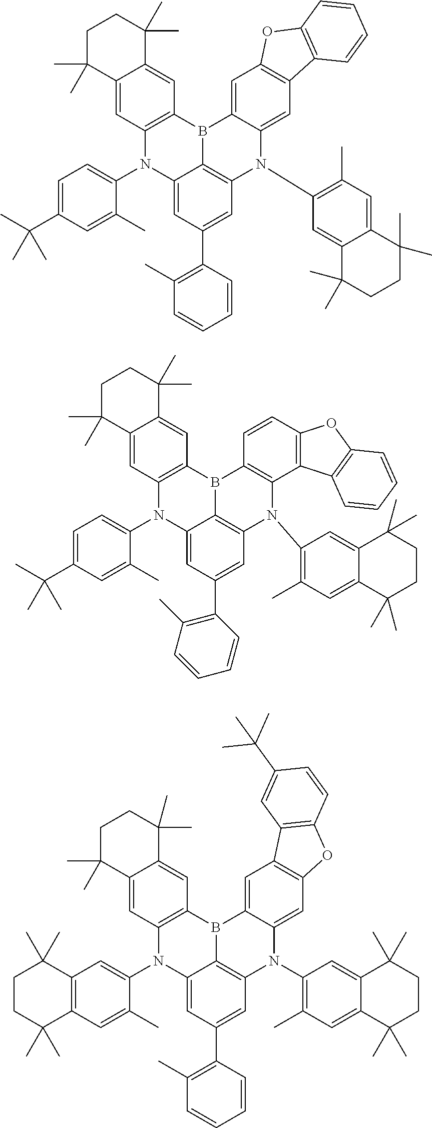

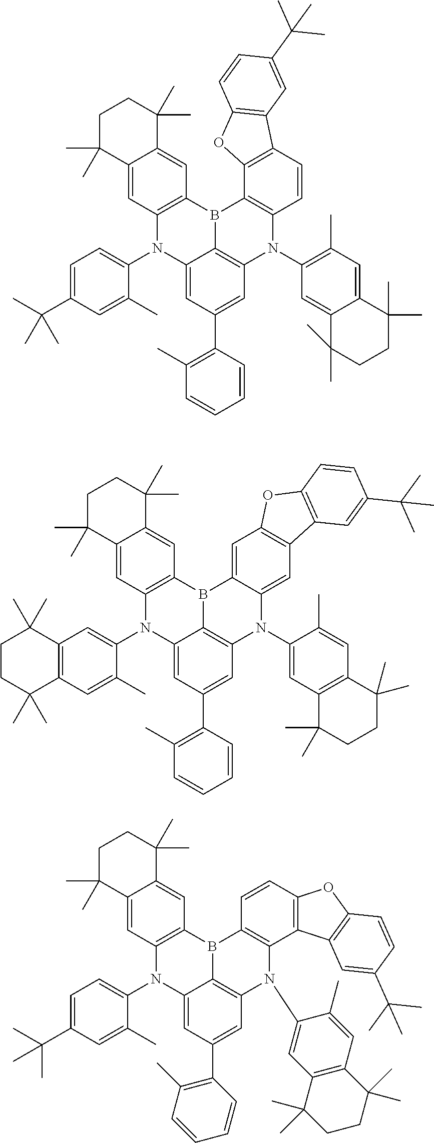

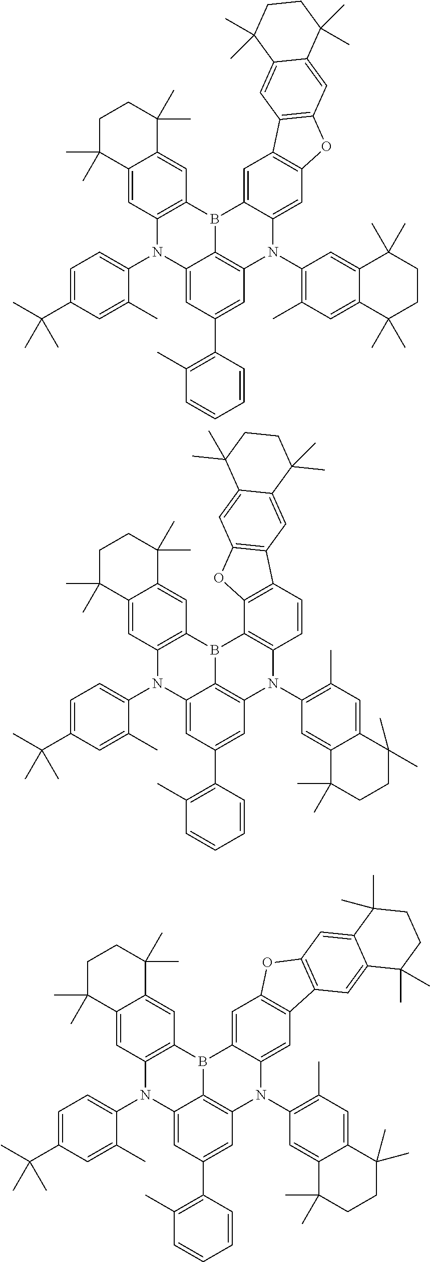

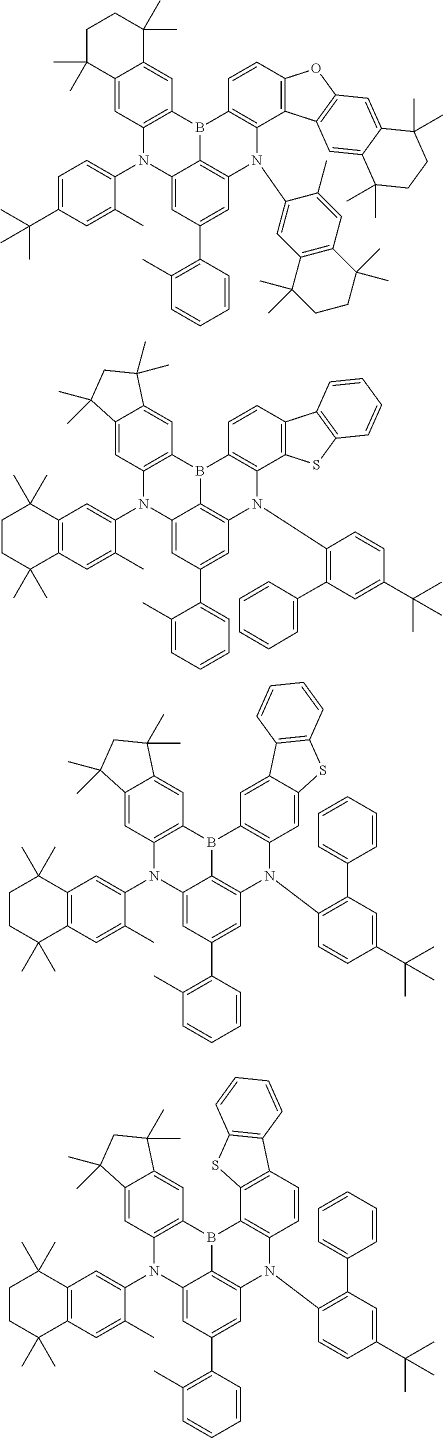

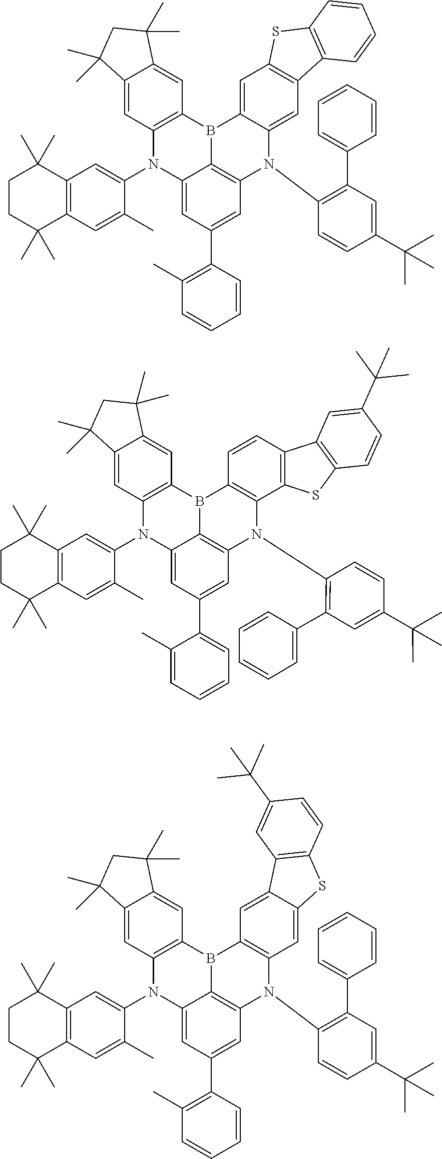 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)sc1ccccc14 ; Cc1ccccc1-c1cc2c3c(c1)N(c1ccc(C(C)(C)C)cc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4sc5ccc(C(C)(C)C)cc5c4cc1B3c1cc3c(cc1N2c1cc2c(cc1C)C(C)(C)CCC2(C)C)C(C)(C)CC3(C)C]

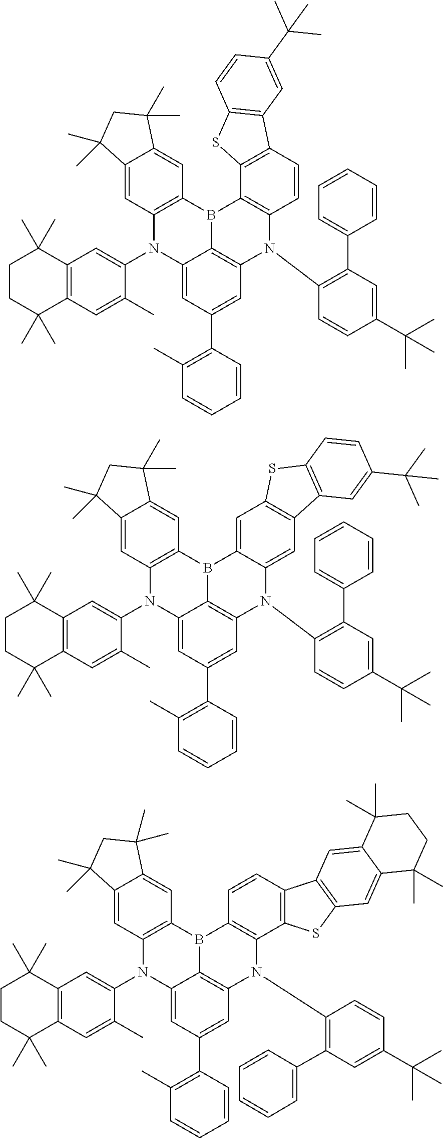 [SMILES: Cc1ccccc1-c1cc2c3c(c1)N(c1ccc(C(C)(C)C)cc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)CC3(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)sc1ccc(C(C)(C)C)cc14 ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C]

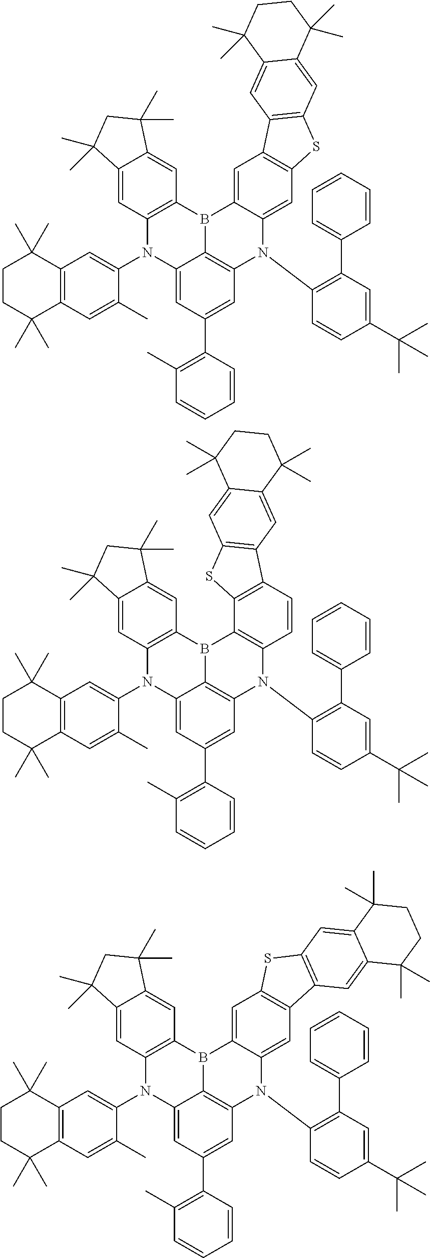

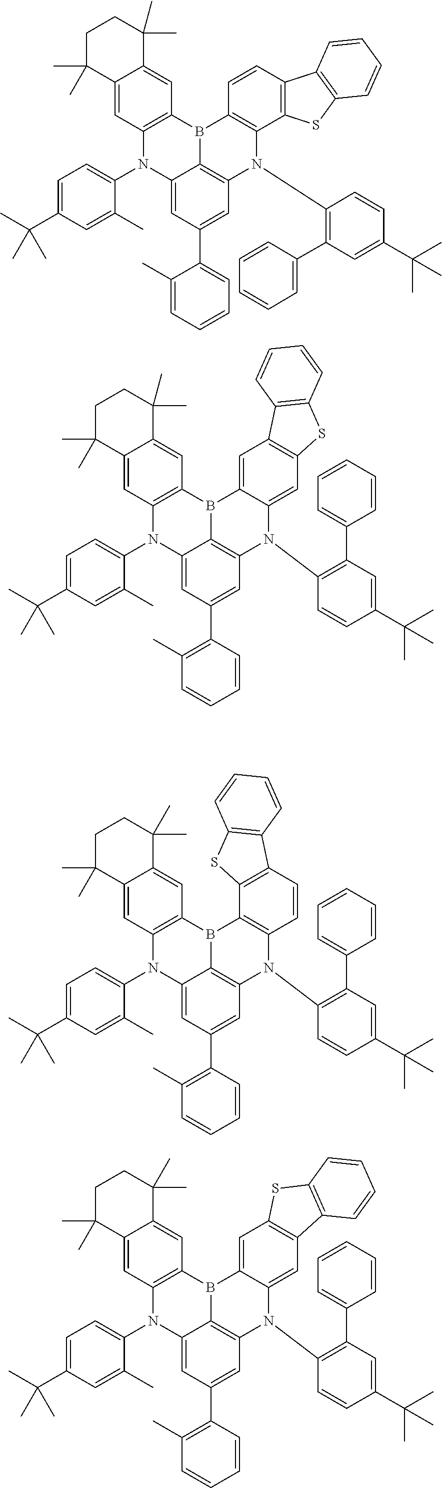

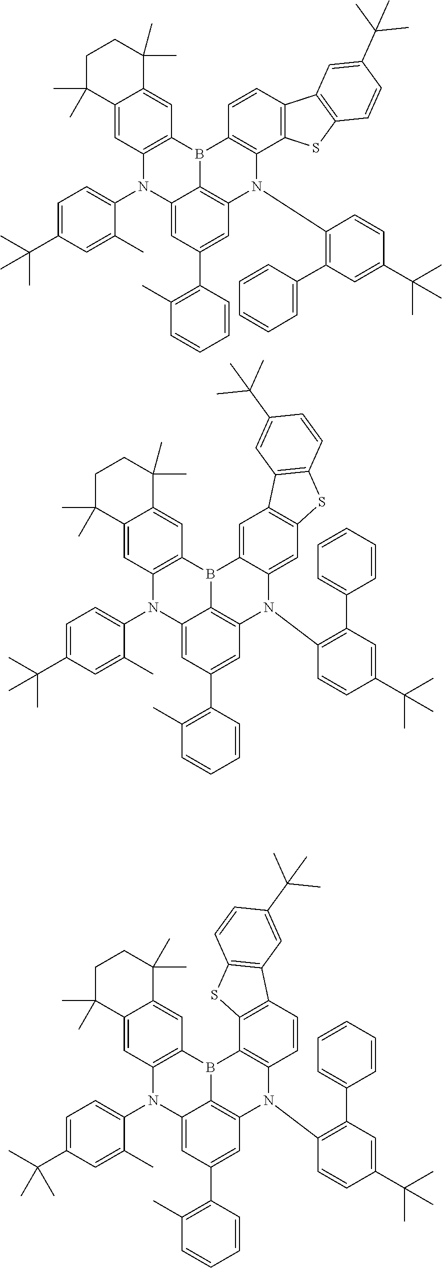

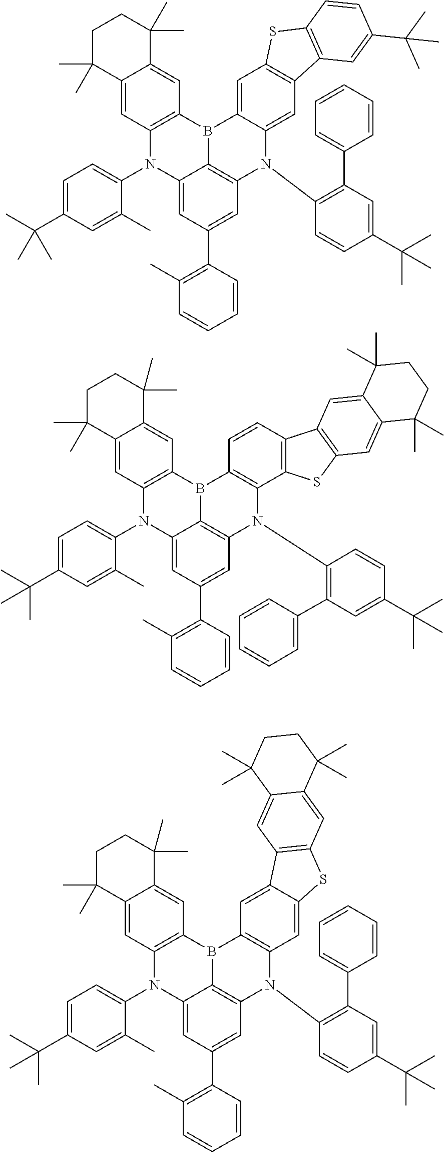

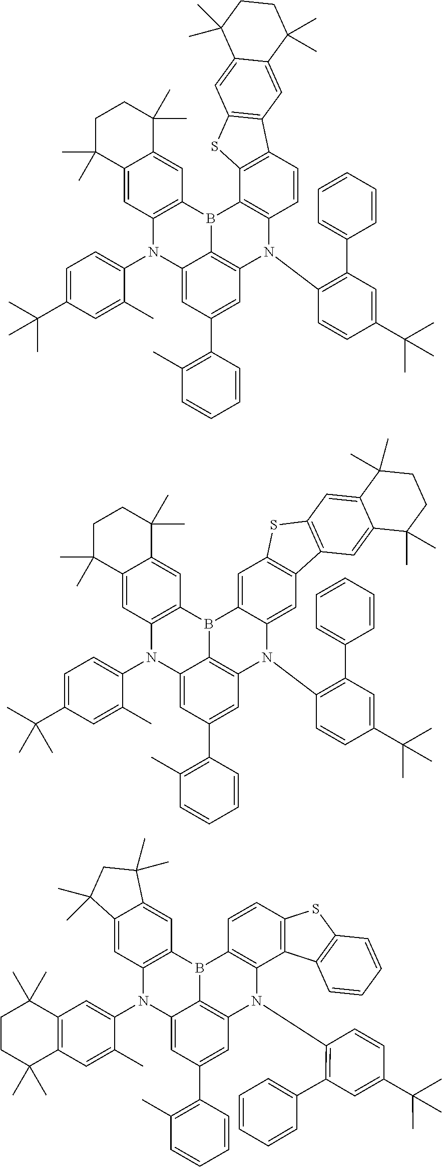

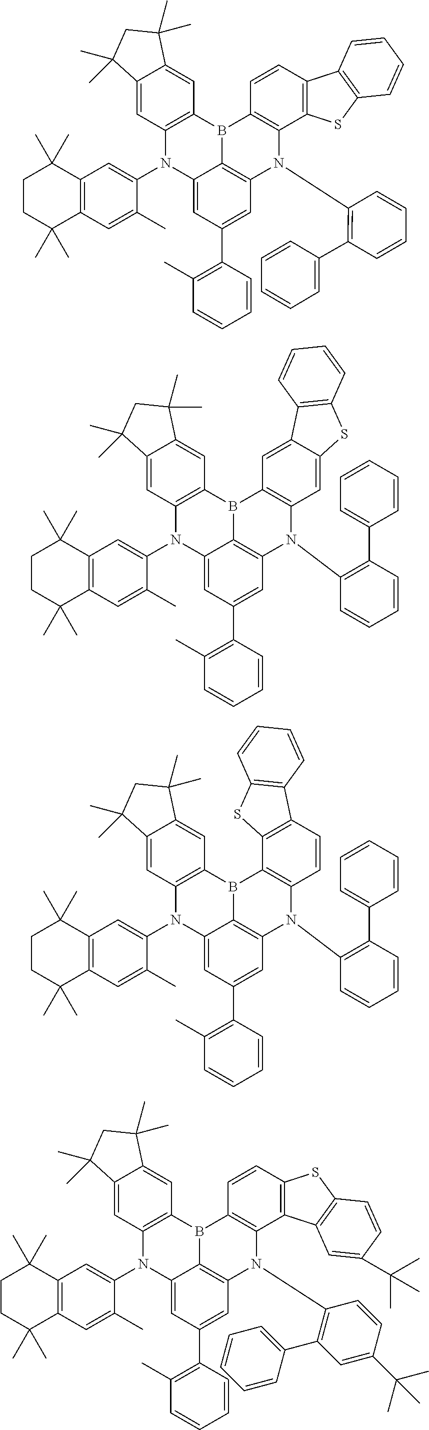

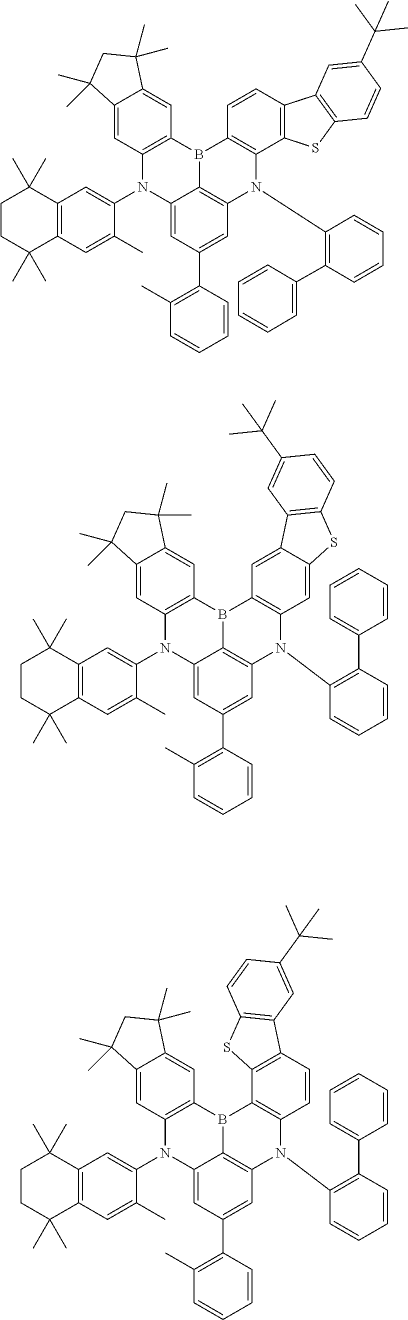 [SMILES: Cc1ccccc1-c1cc2c3c(c1)N(c1ccccc1-c1ccccc1)c1c(ccc4c1sc1ccc(C(C)(C)C)cc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1ccc4c(sc5ccc(C(C)(C)C)cc54)c1B3c1cc3c(cc1N2c1cc2c(cc1C)C(C)(C)CCC2(C)C)C(C)(C)CC3(C)C]

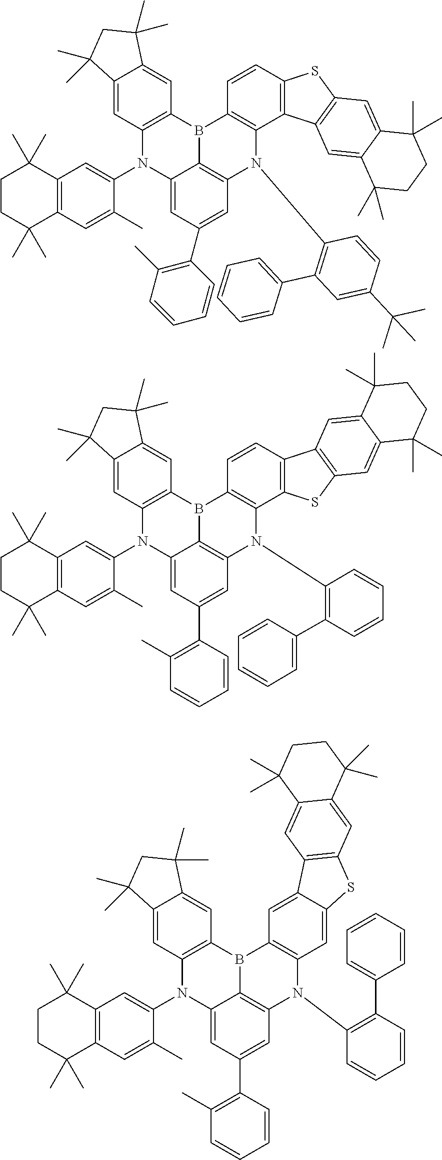

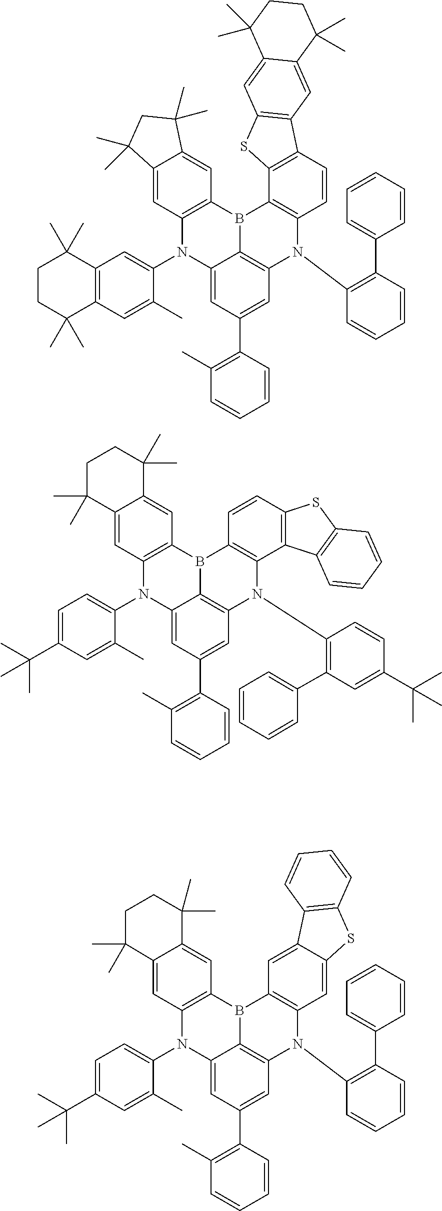

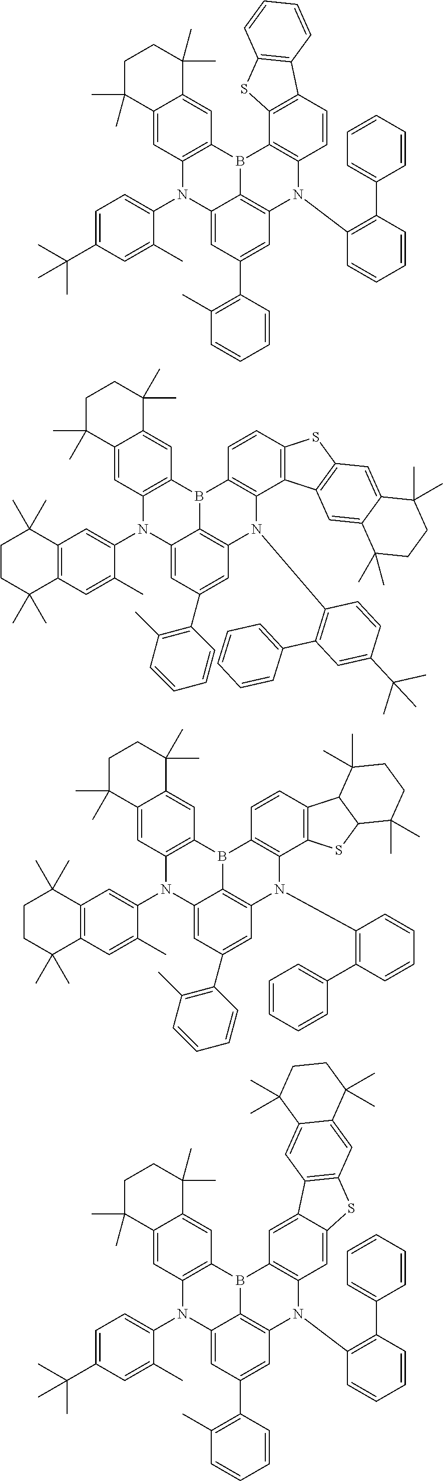

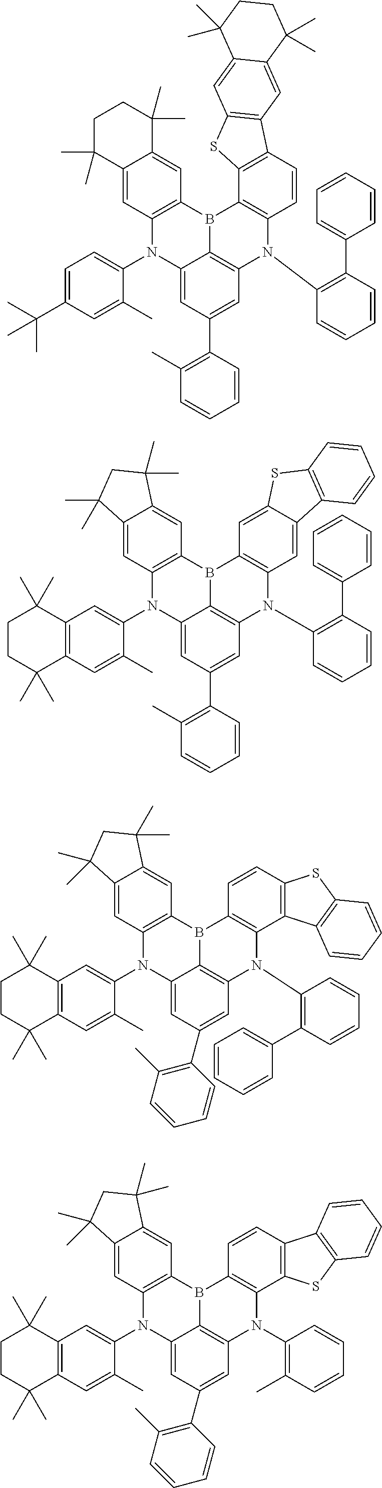

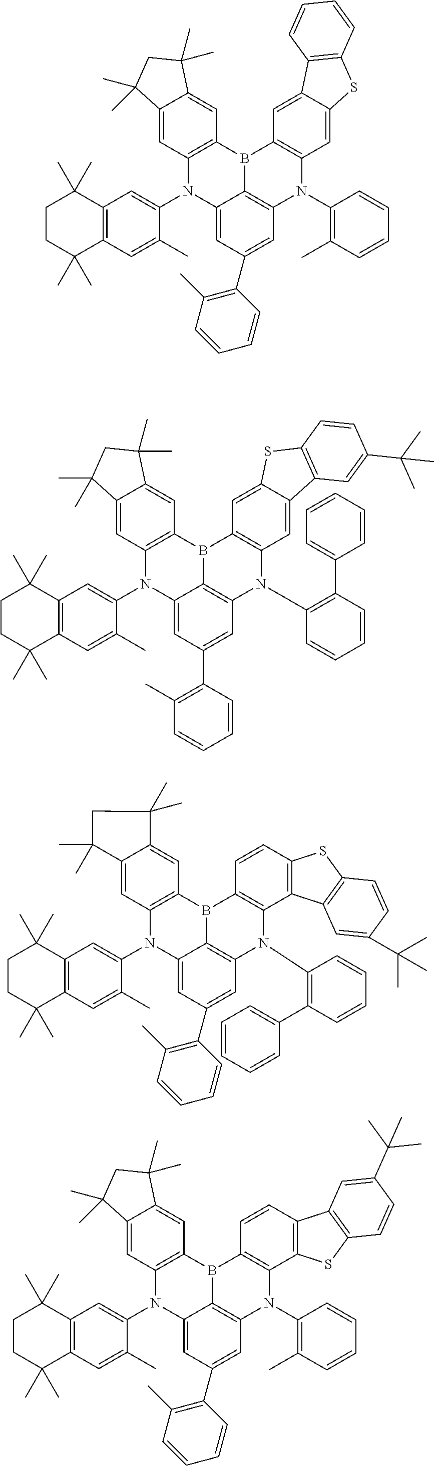

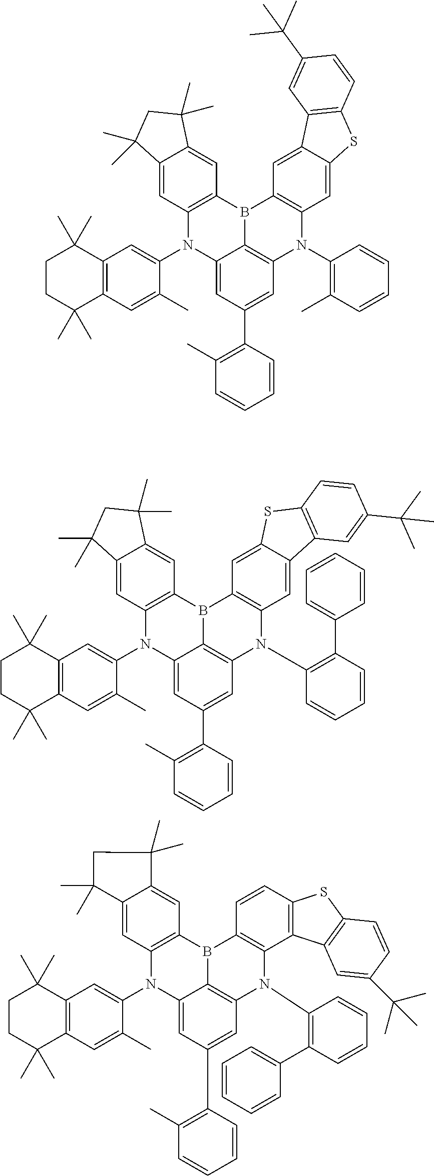

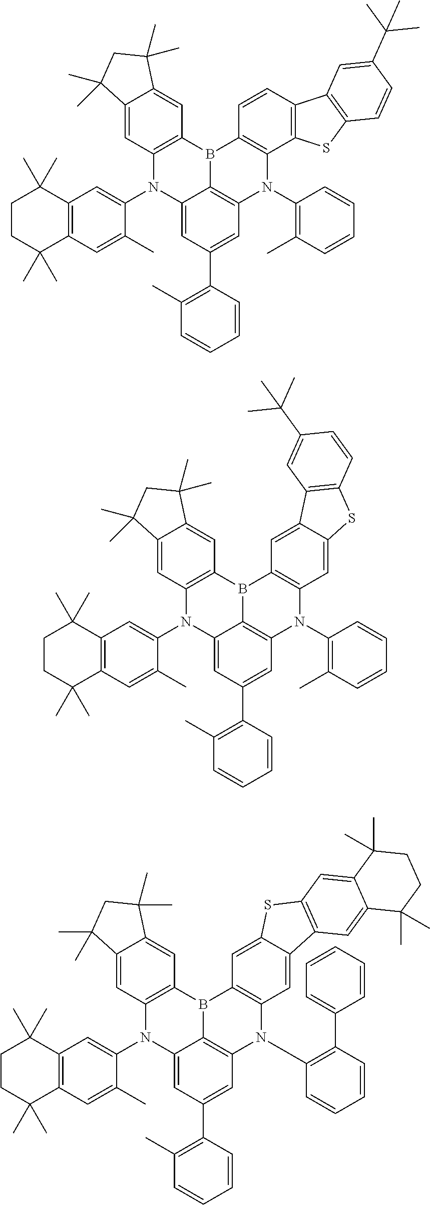 [SMILES: Cc1ccccc1-c1cc2c3c(c1)N(c1ccccc1C)c1c(ccc4c1sc1ccc(C(C)(C)C)cc14)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4sc5ccc(C(C)(C)C)cc5c4cc1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1-c1ccccc1)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C]

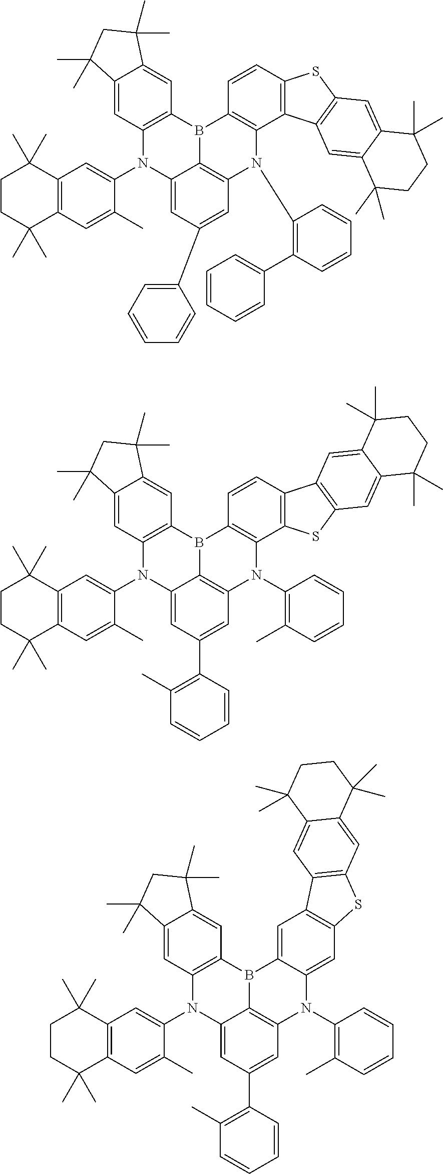 [SMILES: Cc1cc2c(cc1N1c3cc4c(cc3B3c5ccc6sc7cc8c(cc7c6c5N(c5ccccc5-c5ccccc5)c5cc(-c6ccccc6)cc1c53)C(C)(C)CCC8(C)C)C(C)(C)CC4(C)C)C(C)(C)CCC2(C)C ; Cc1ccccc1-c1cc2c3c(c1)N(c1ccccc1C)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C]

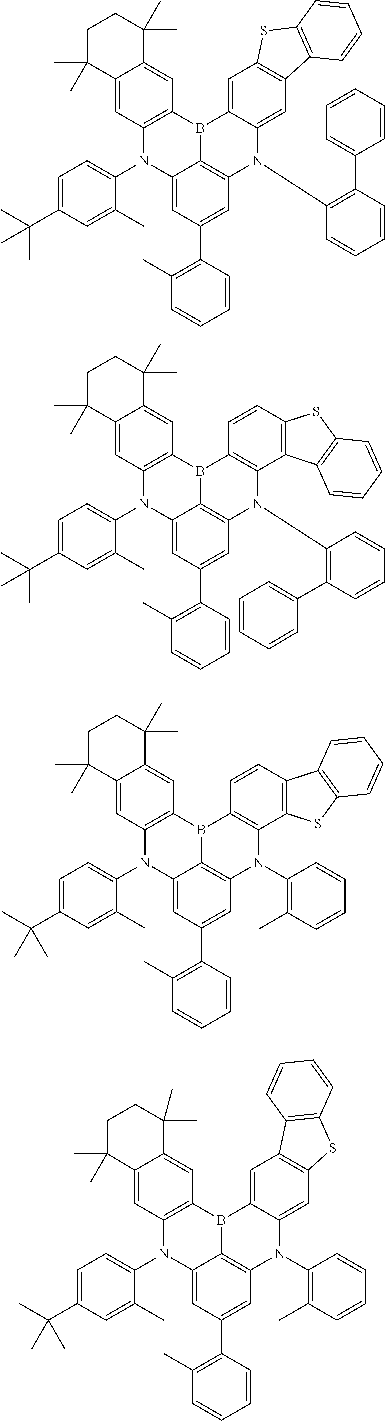

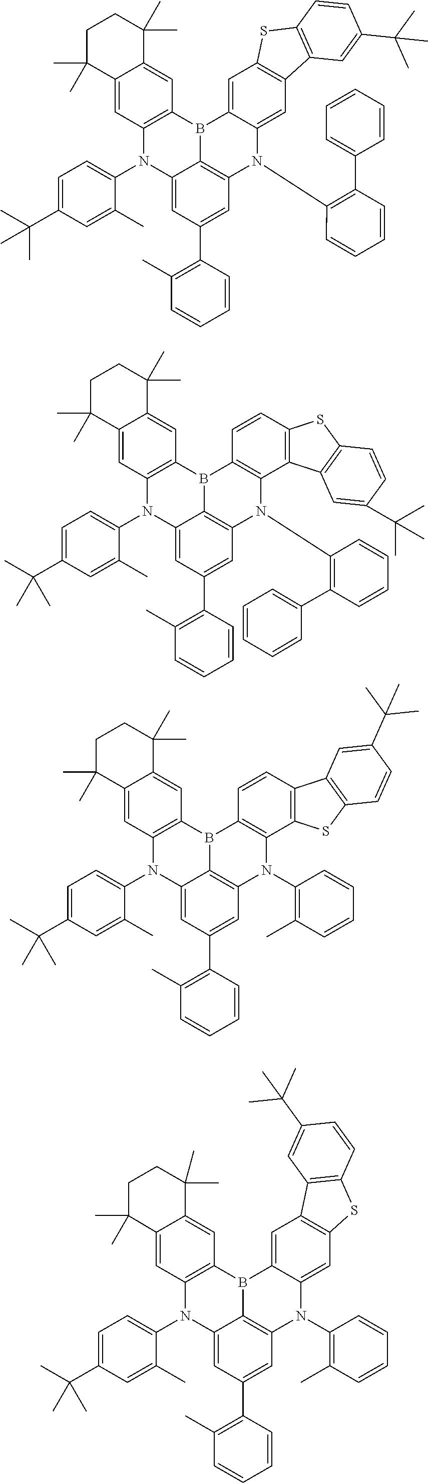

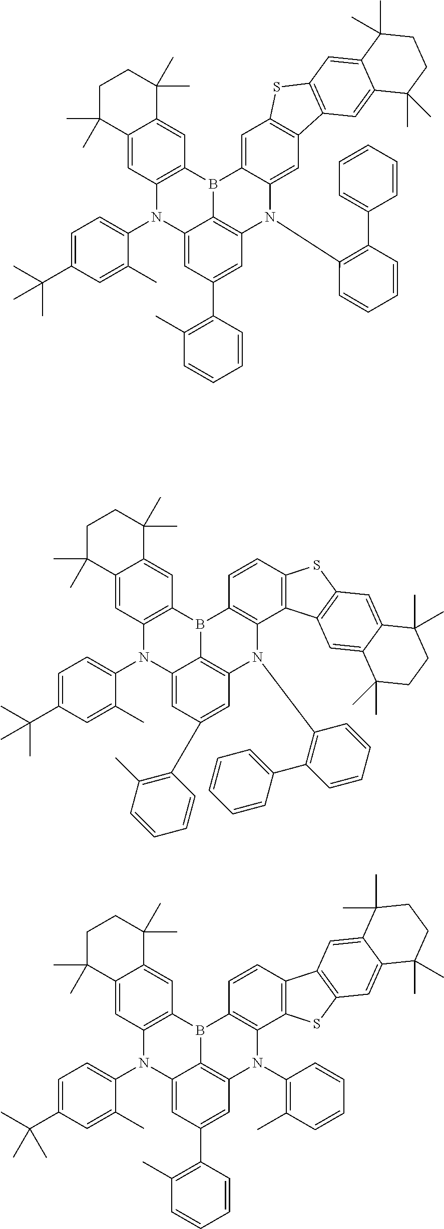

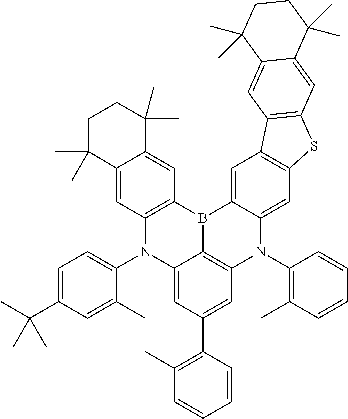 [SMILES: Cc1ccccc1-c1cc2c3c(c1)N(c1ccccc1C)c1cc4sc5cc6c(cc5c4cc1B3c1cc3c(cc1N2c1ccc(C(C)(C)C)cc1C)C(C)(C)CCC3(C)C)C(C)(C)CCC6(C)C]

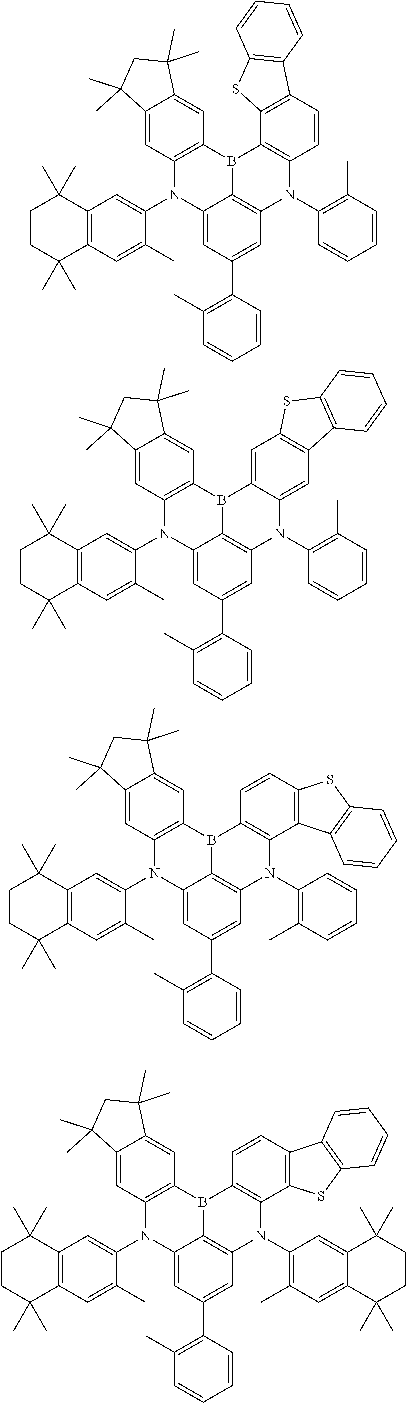

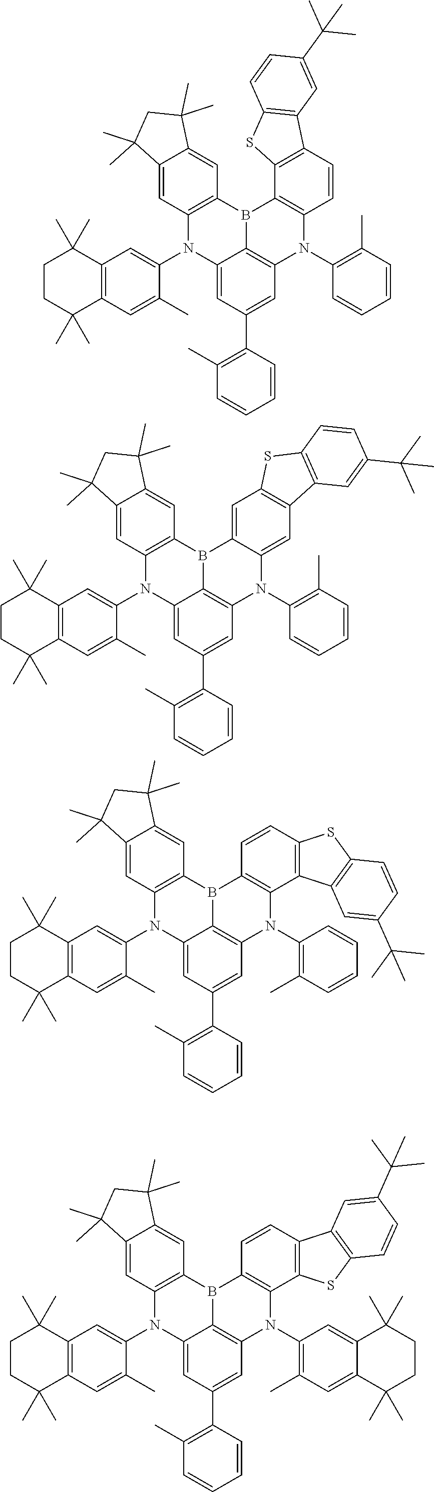

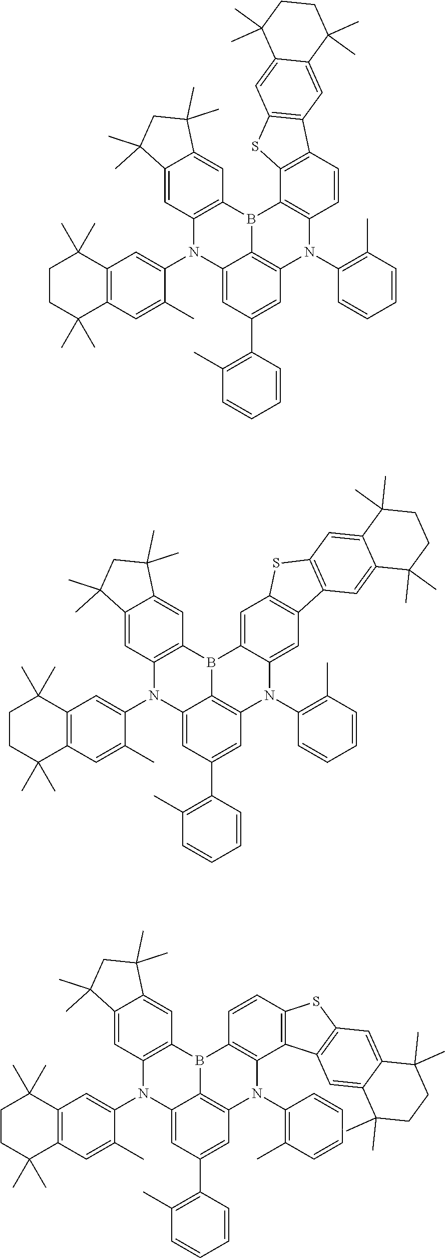 [SMILES: Cc1ccccc1-c1cc2c3c(c1)N(c1ccccc1C)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1ccccc1-c1cc2c3c(c1)N(c1ccccc1C)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C ; Cc1ccccc1-c1cc2c3c(c1)N(c1ccccc1C)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C]

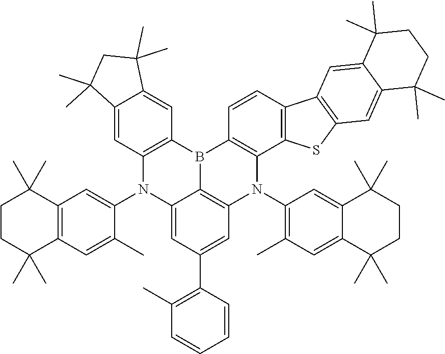 [SMILES: Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc3c(cc1N2c1cc2c(cc1C)C(C)(C)CCC2(C)C)C(C)(C)CC3(C)C]

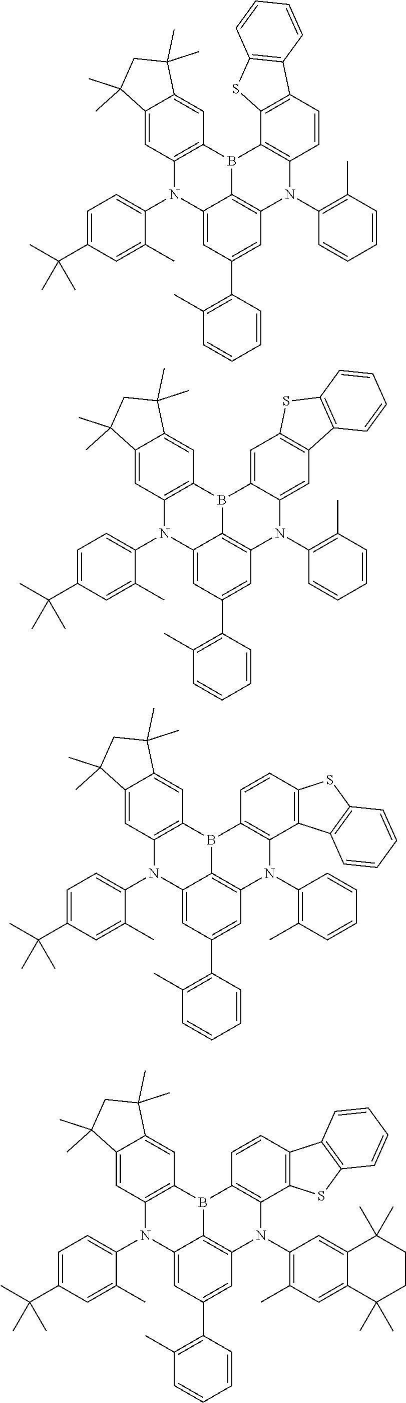

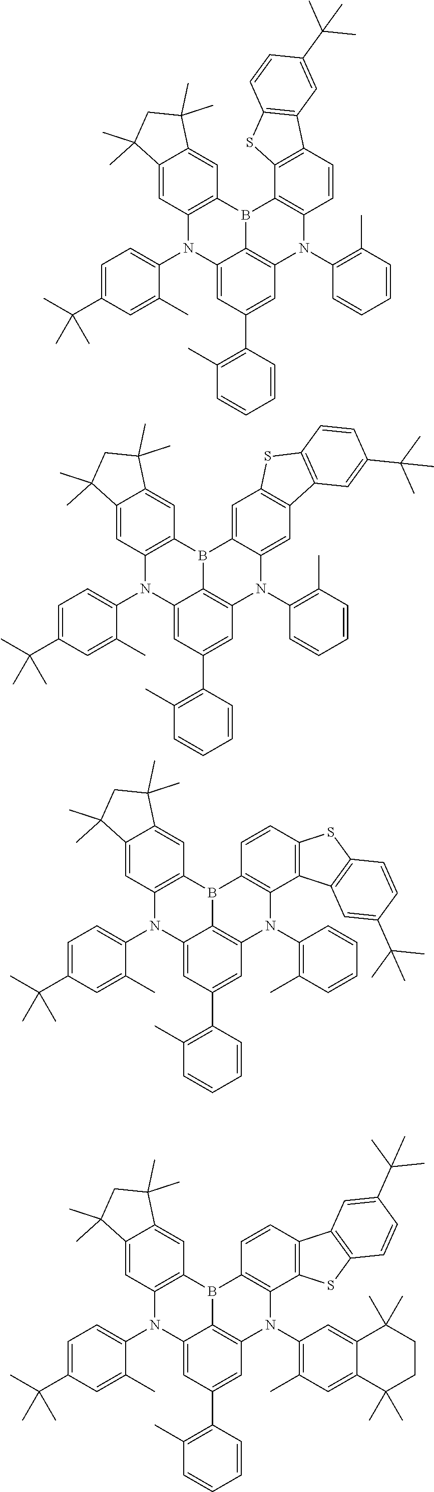

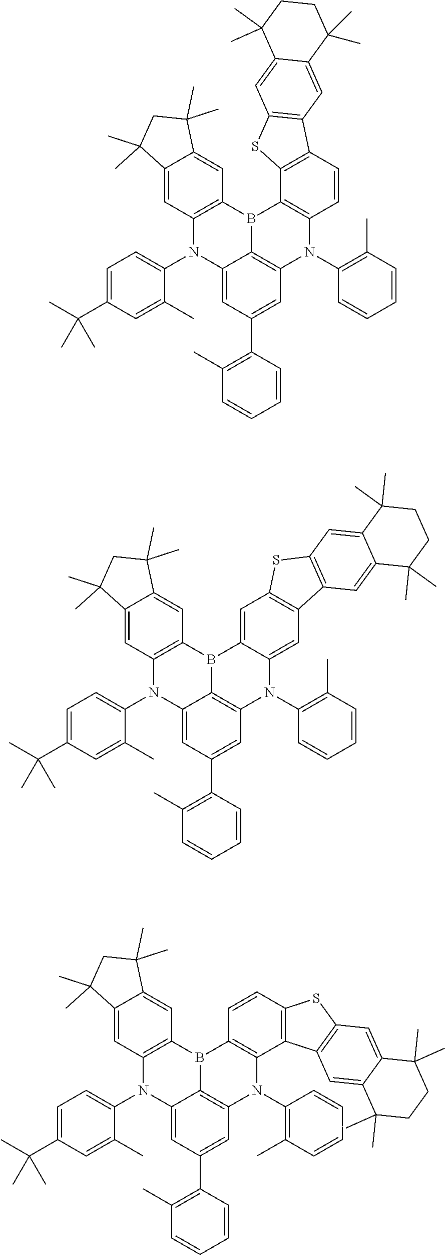

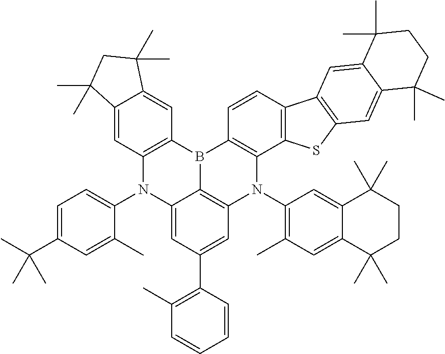 [SMILES: Cc1ccccc1-c1cc2c3c(c1)N(c1cc4c(cc1C)C(C)(C)CCC4(C)C)c1c(ccc4c1sc1cc5c(cc14)C(C)(C)CCC5(C)C)B3c1cc3c(cc1N2c1ccc(C(C)(C)C)cc1C)C(C)(C)CC3(C)C]

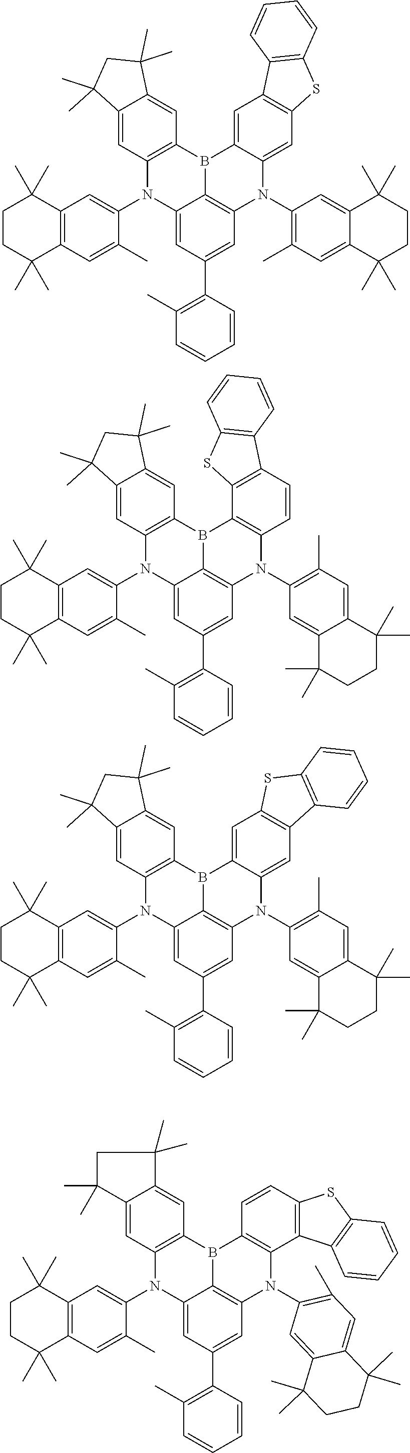

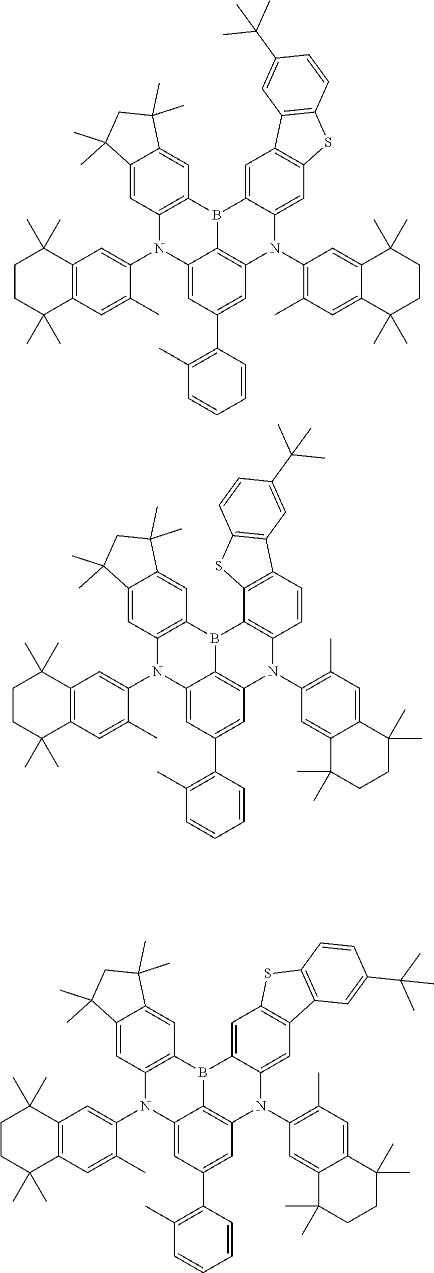

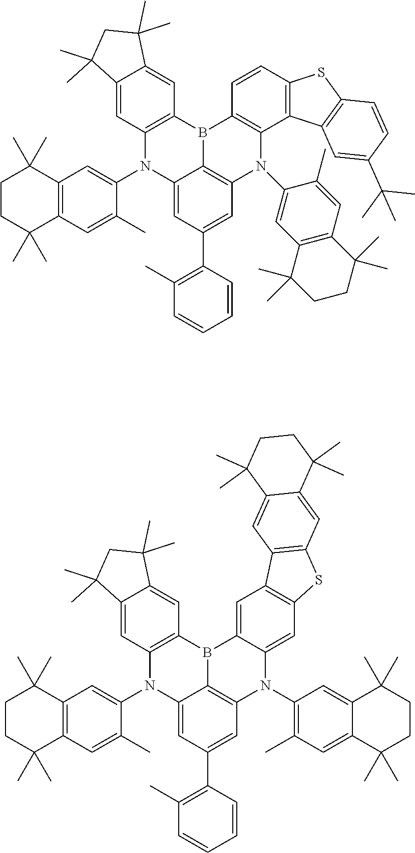 [SMILES: Cc1ccccc1-c1cc2c3c(c1)N(c1cc4c(cc1C)C(C)(C)CCC4(C)C)c1c(ccc4sc5ccc(C(C)(C)C)cc5c14)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4sc5cc6c(cc5c4cc1B3c1cc3c(cc1N2c1cc2c(cc1C)C(C)(C)CCC2(C)C)C(C)(C)CC3(C)C)C(C)(C)CCC6(C)C]

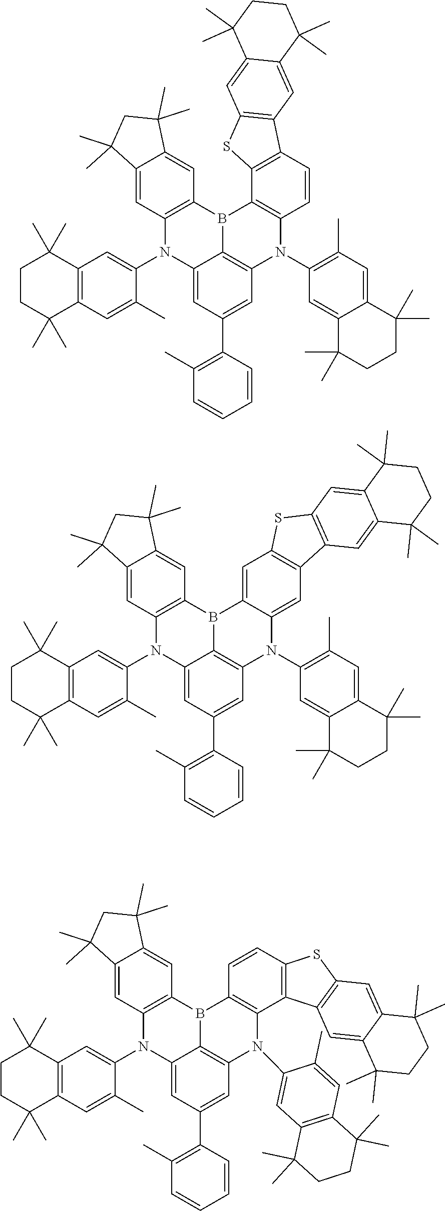 [SMILES: Cc1ccccc1-c1cc2c3c(c1)N(c1cc4c(cc1C)C(C)(C)CCC4(C)C)c1ccc4c(sc5cc6c(cc54)C(C)(C)CCC6(C)C)c1B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)sc1cc2c(cc14)C(C)(C)CCC2(C)C ; Cc1ccccc1-c1cc2c3c(c1)N(c1cc4c(cc1C)C(C)(C)CCC4(C)C)c1c(ccc4sc5cc6c(cc5c14)C(C)(C)CCC6(C)C)B3c1cc3c(cc1N2c1cc2c(cc1C)C(C)(C)CCC2(C)C)C(C)(C)CC3(C)C]

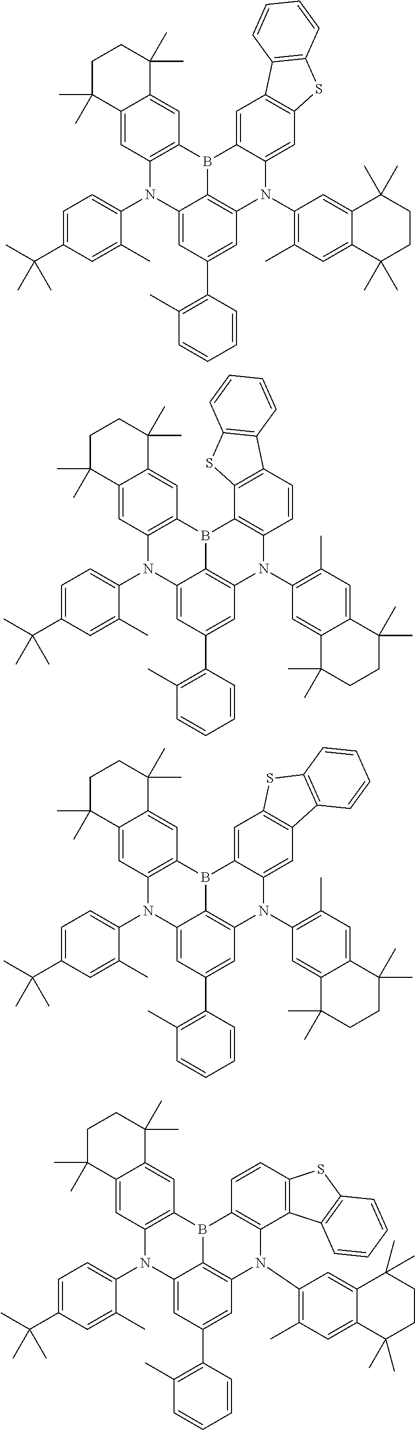

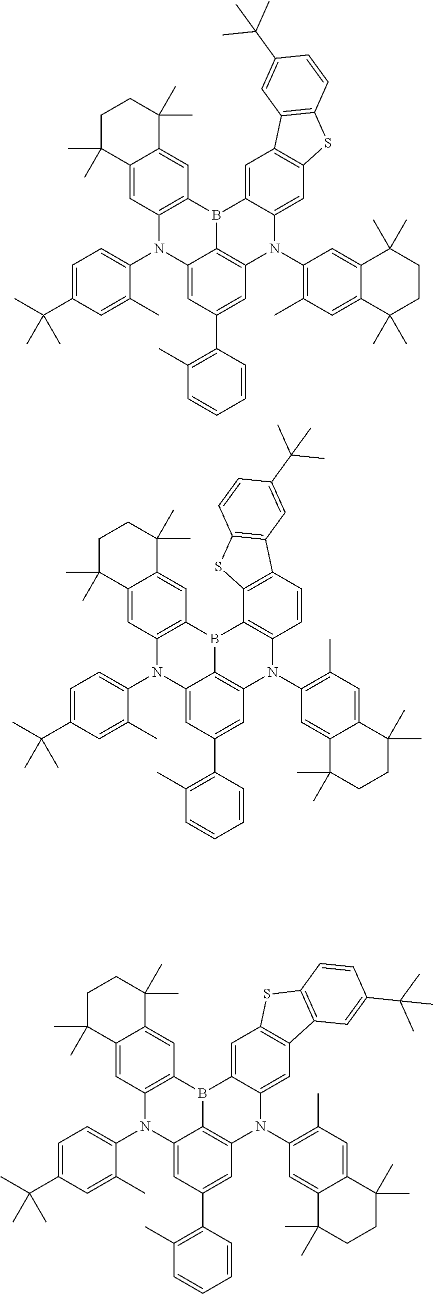

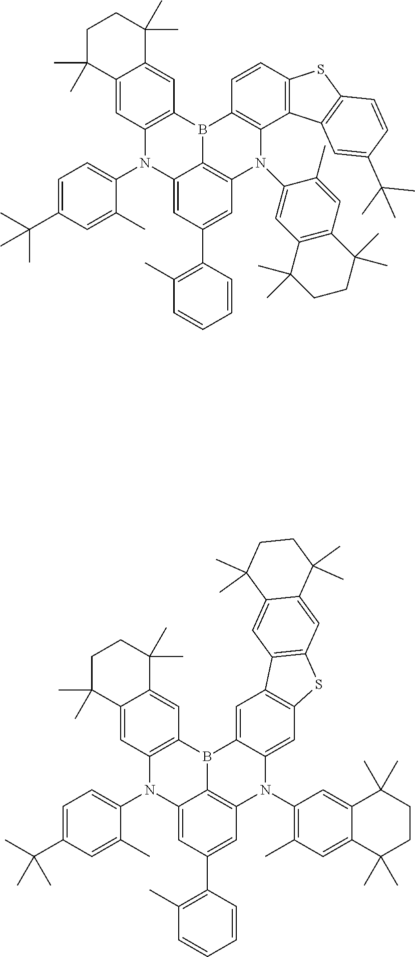

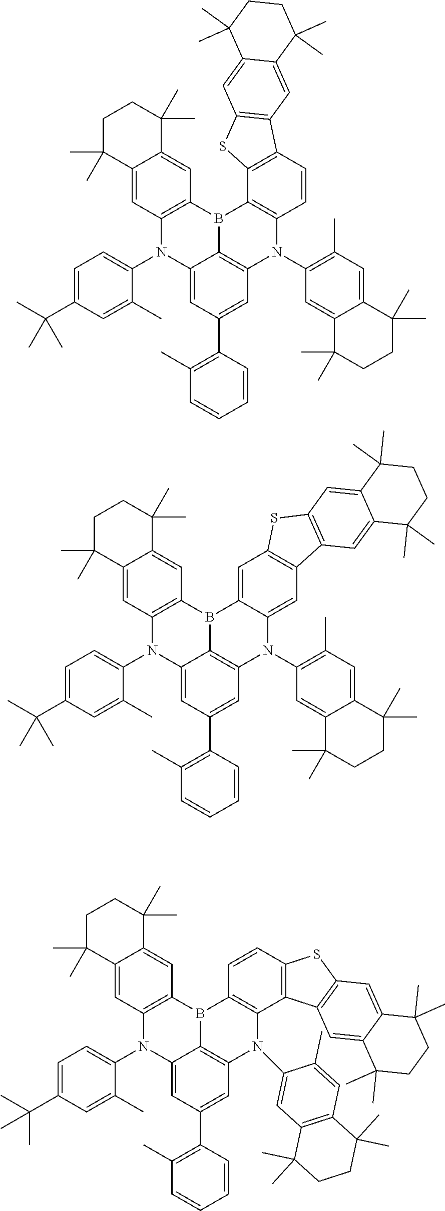

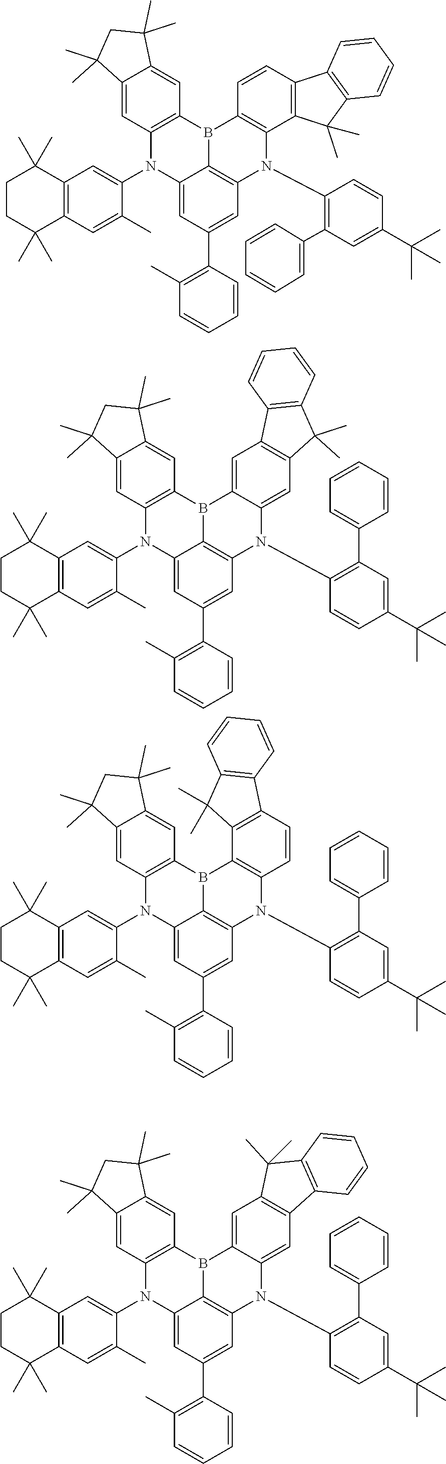

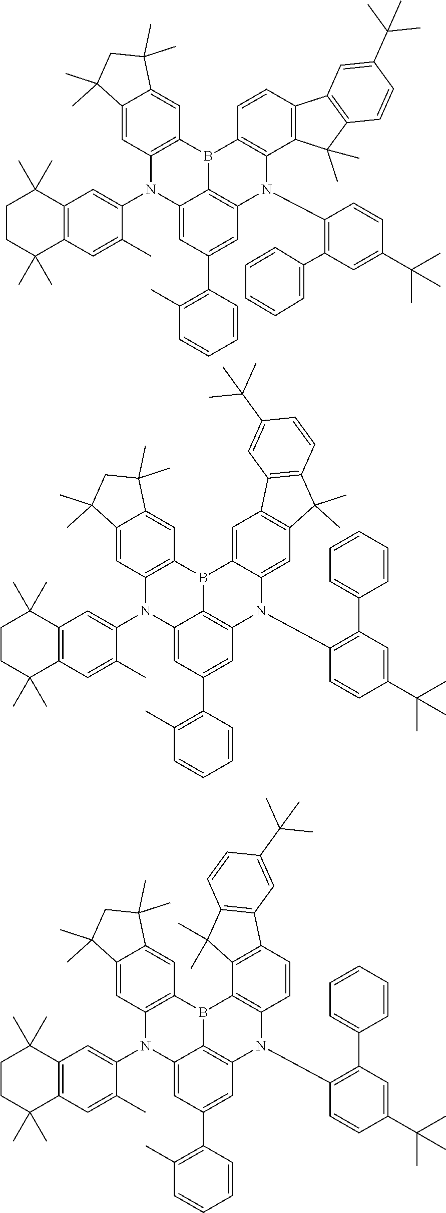

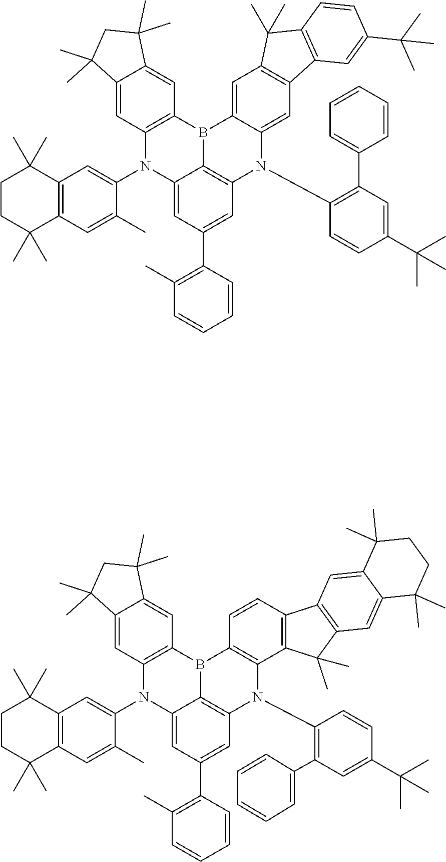 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CC3(C)C]

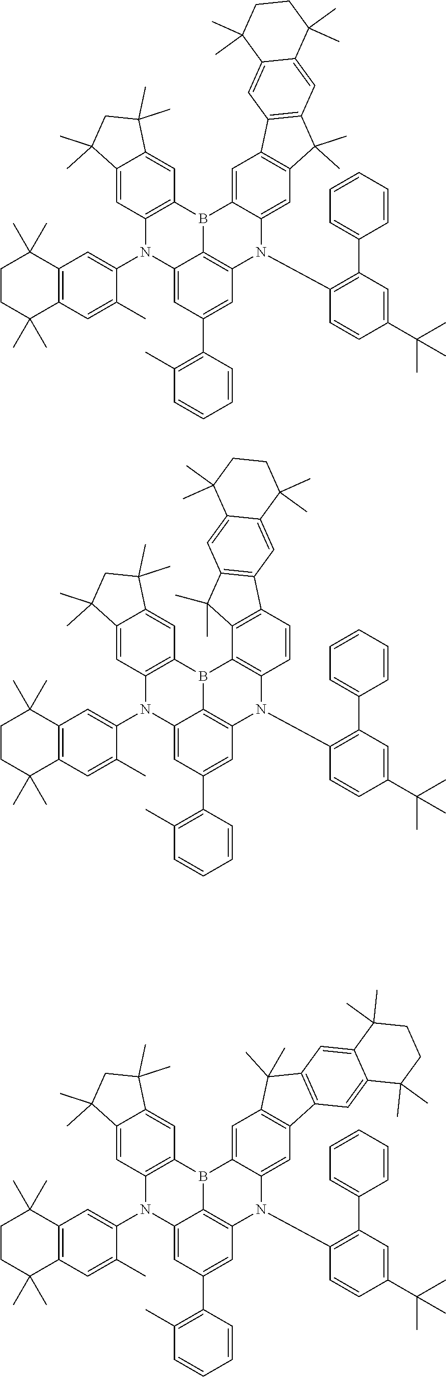 [SMILES: Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C ; Cc1ccccc1-c1cc2c3c(c1)N(c1ccc(C(C)(C)C)cc1-c1ccccc1)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1ccccc1-c1cc2c3c(c1)N(c1ccc(C(C)(C)C)cc1-c1ccccc1)c1cc4c(cc1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

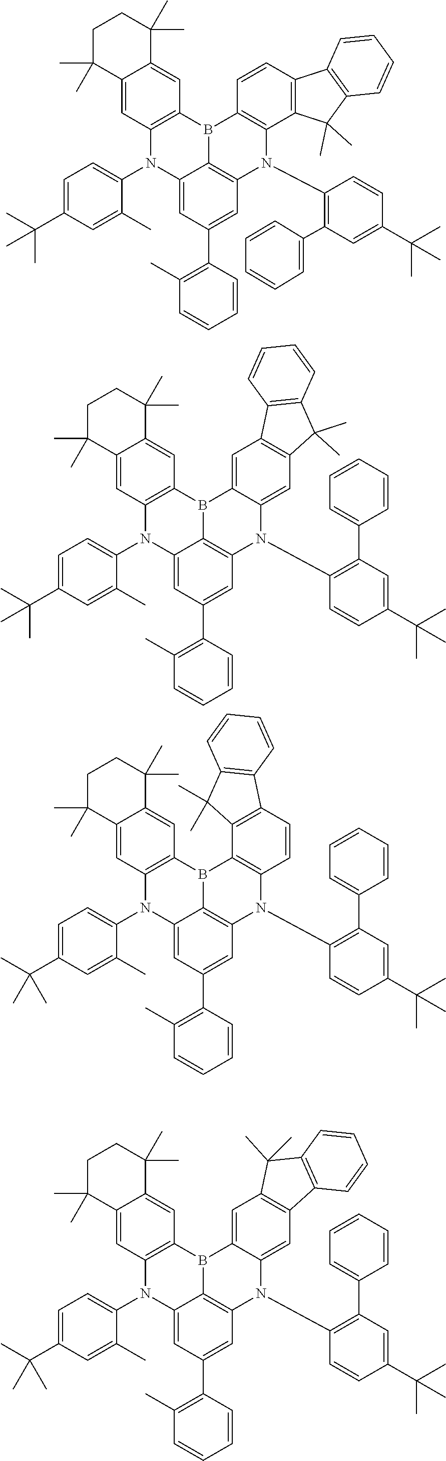

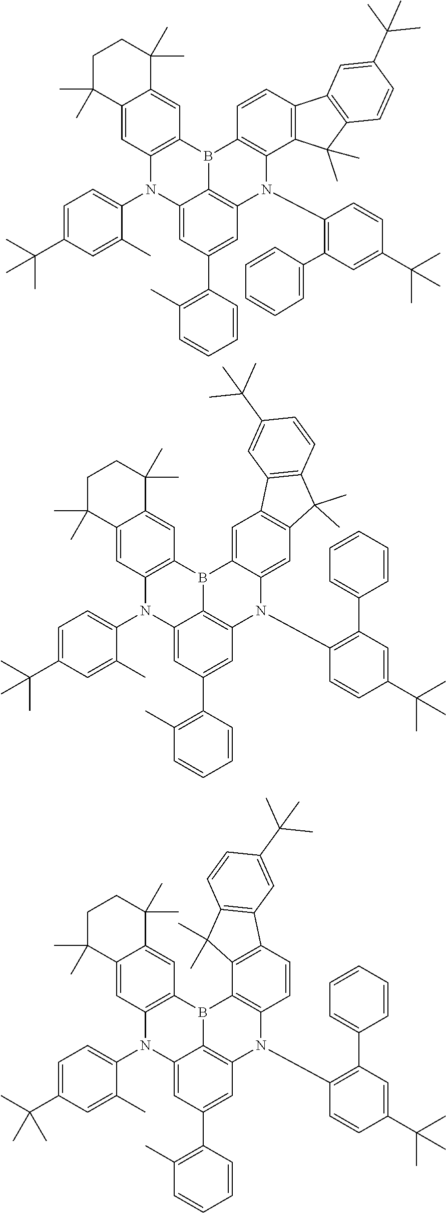

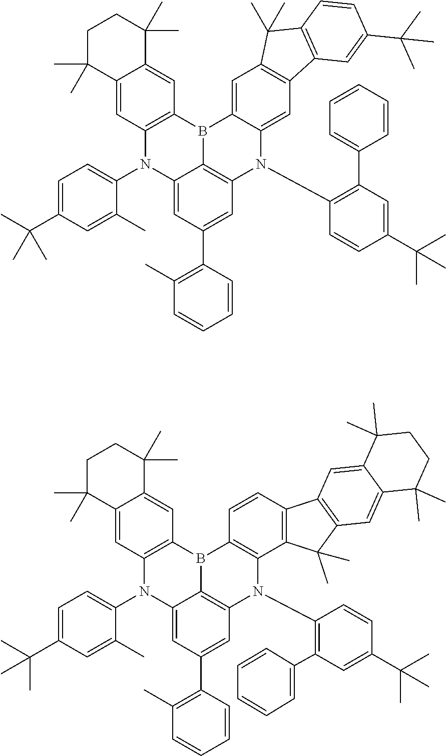

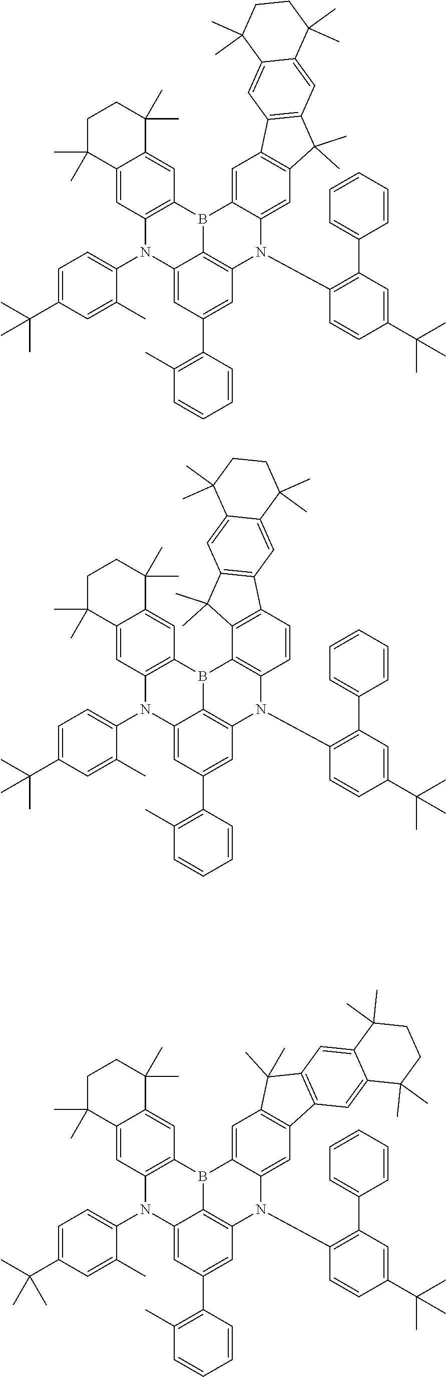

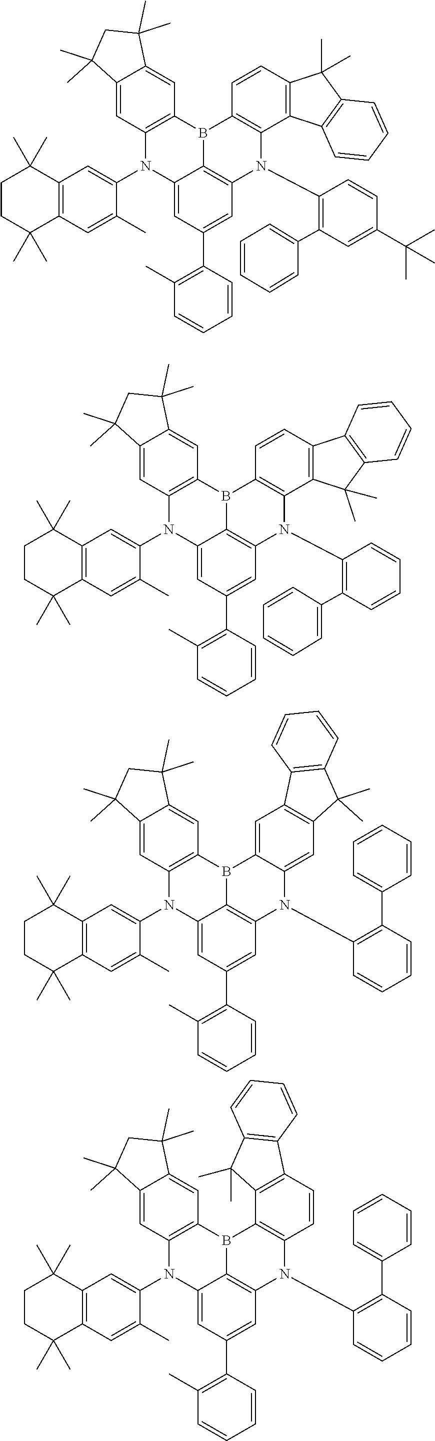

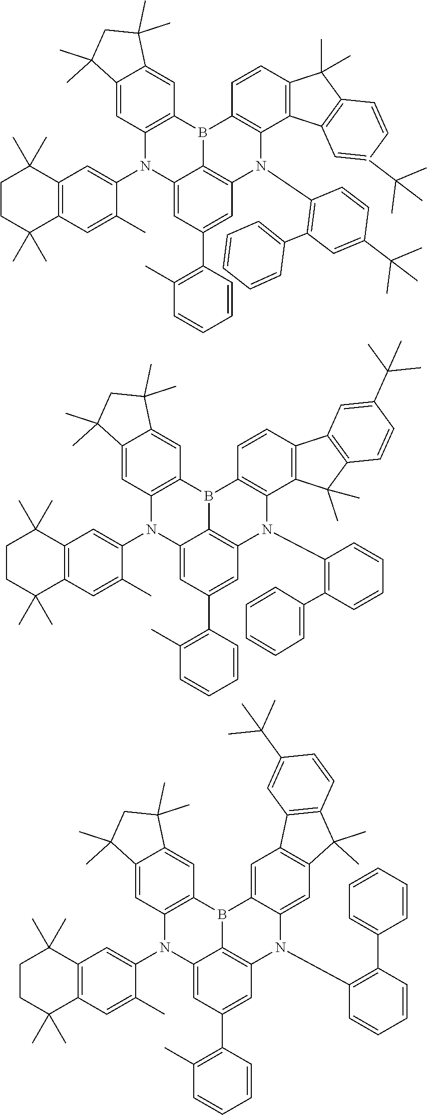

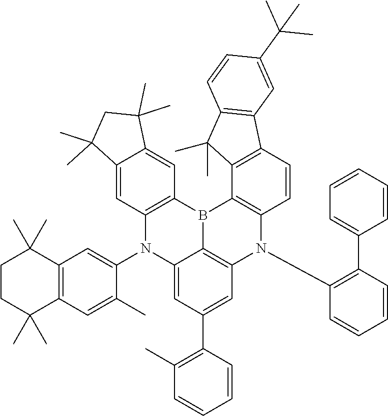 [SMILES: Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1ccc(C(C)(C)C)cc1-4]

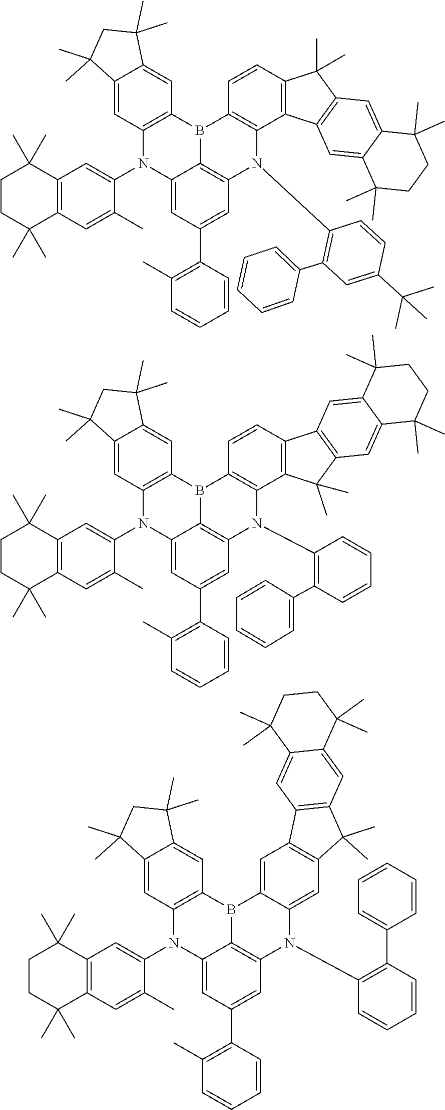

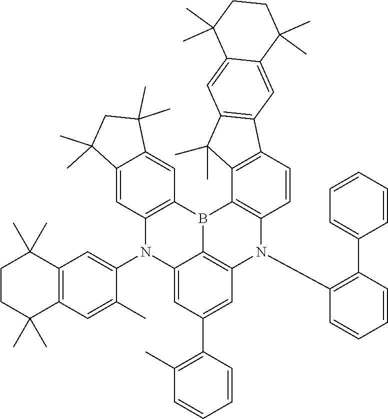 [SMILES: Cc1ccccc1-c1cc2c3c(c1)N(c1ccccc1-c1ccccc1)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C]

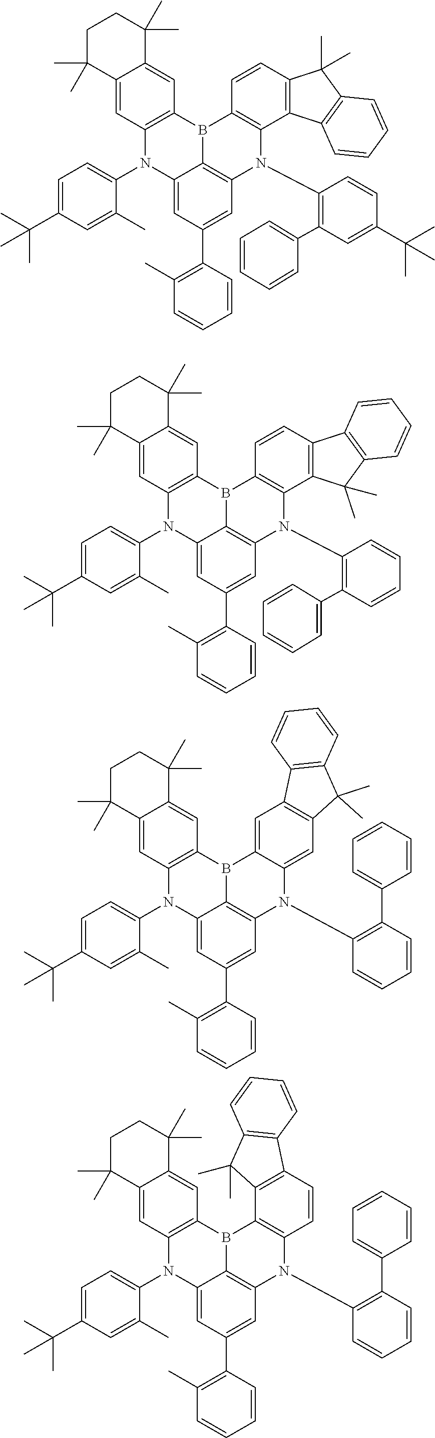

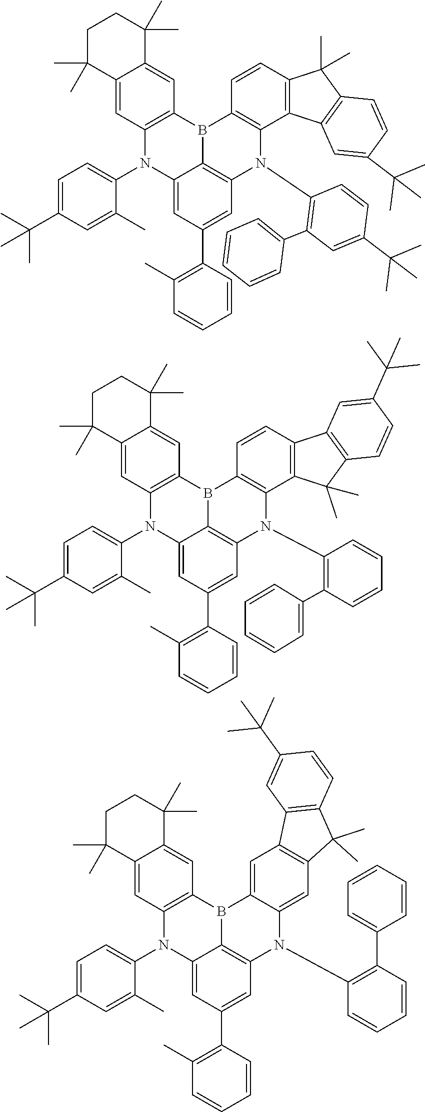

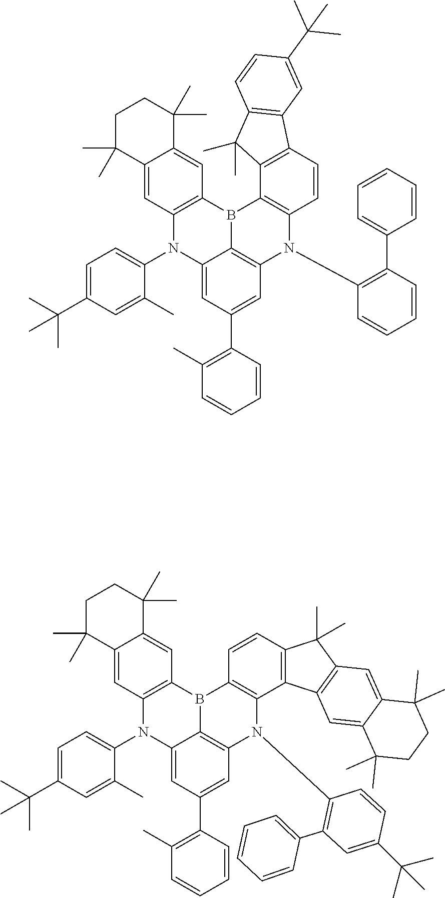 [SMILES: Cc1ccccc1-c1cc2c3c(c1)N(c1ccccc1-c1ccccc1)c1ccc4c(c1B3c1cc3c(cc1N2c1ccc(C(C)(C)C)cc1C)C(C)(C)CCC3(C)C)C(C)(C)c1ccc(C(C)(C)C)cc1-4 ; Cc1ccccc1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1ccc(C(C)(C)C)cc1C)C(C)(C)CCC3(C)C]

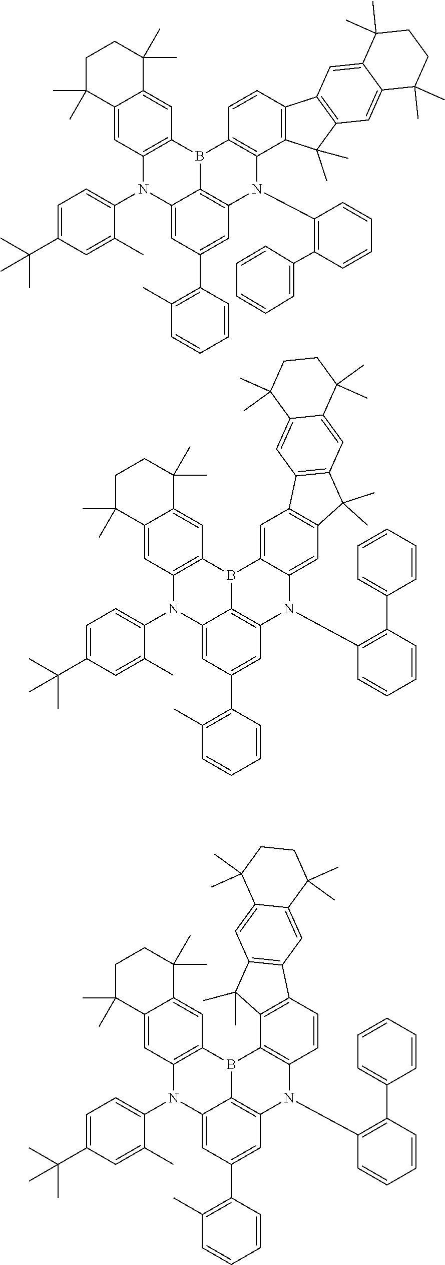

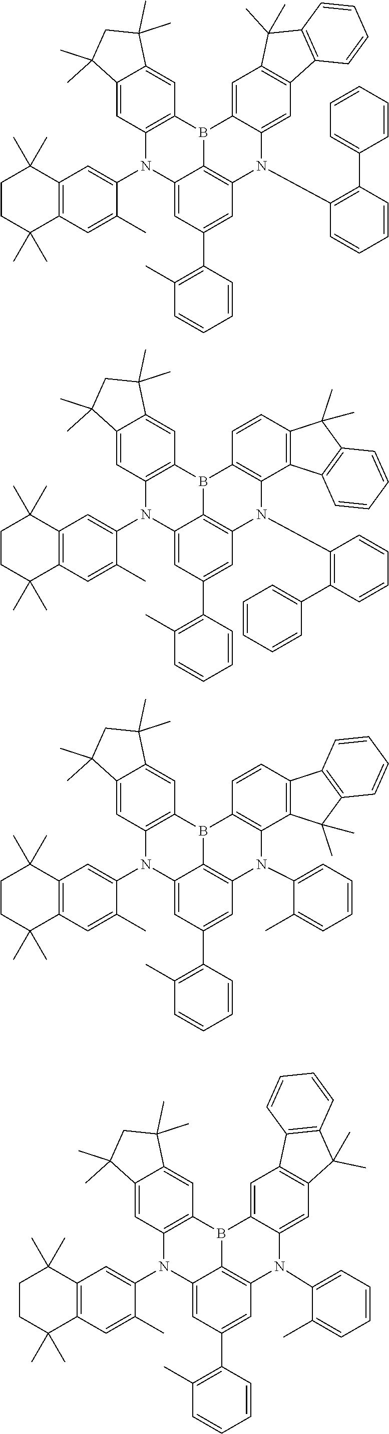

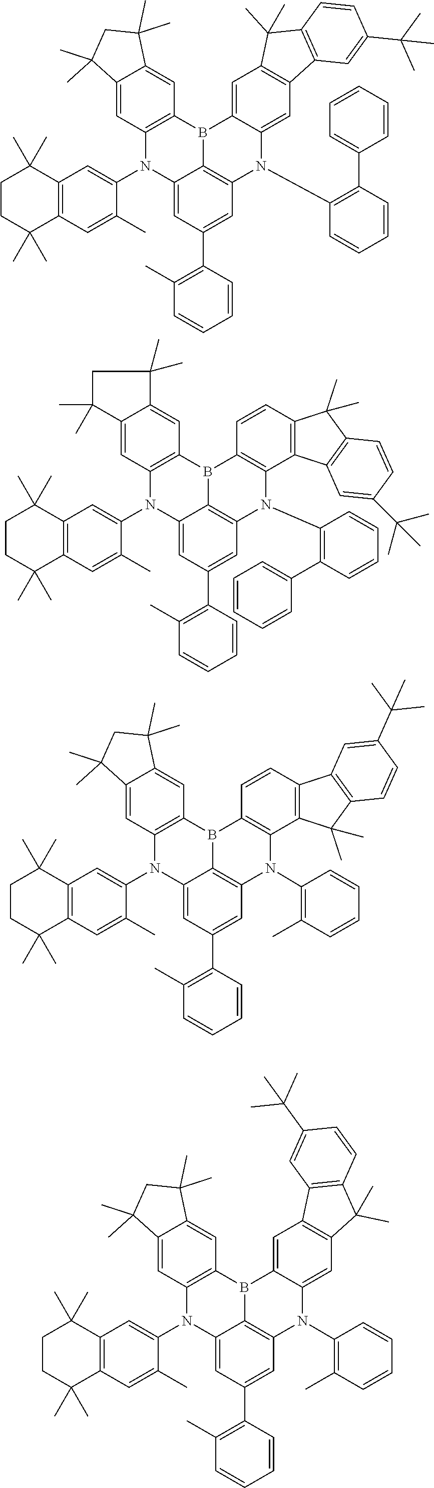

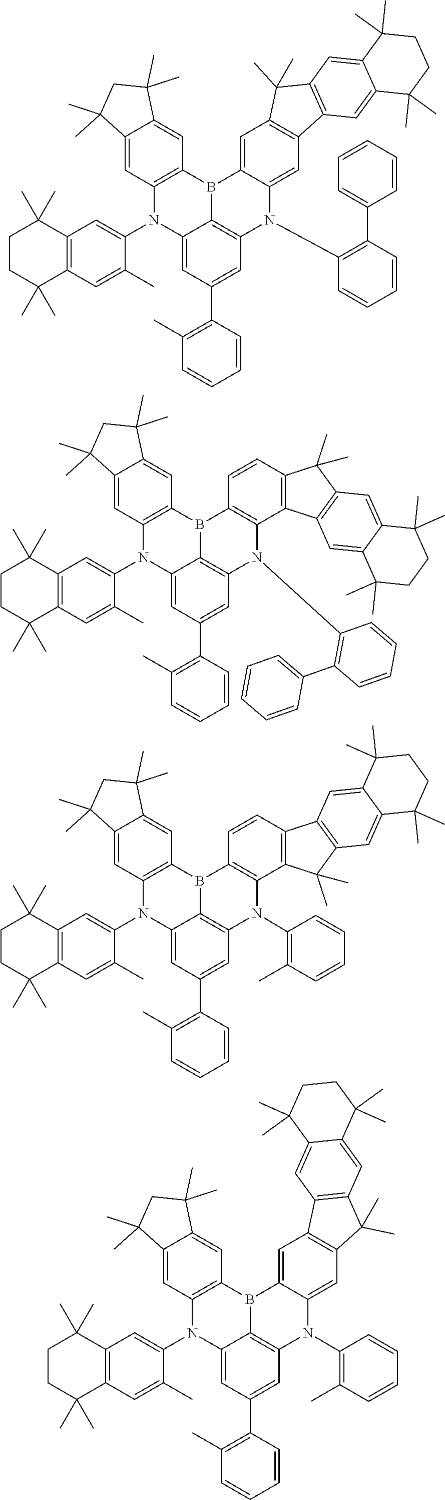

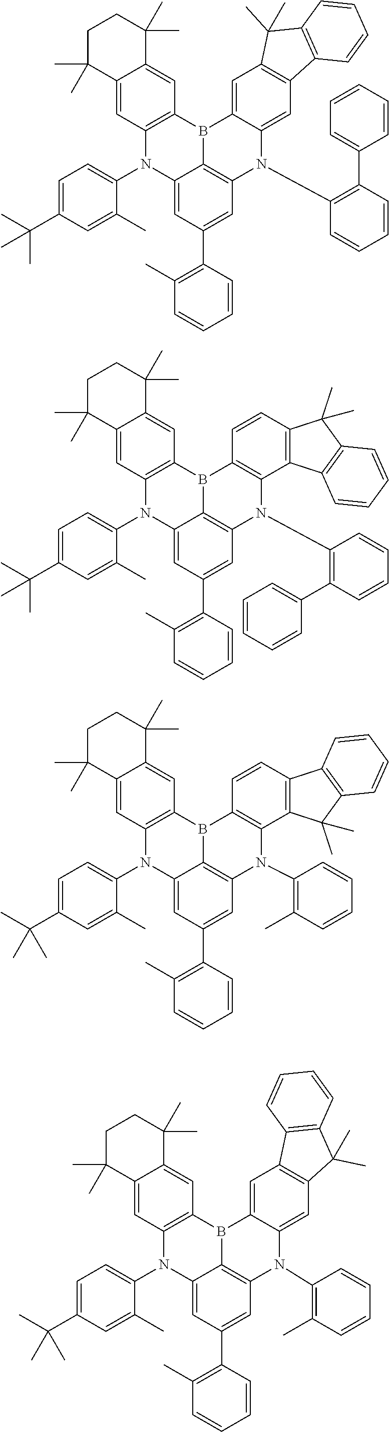

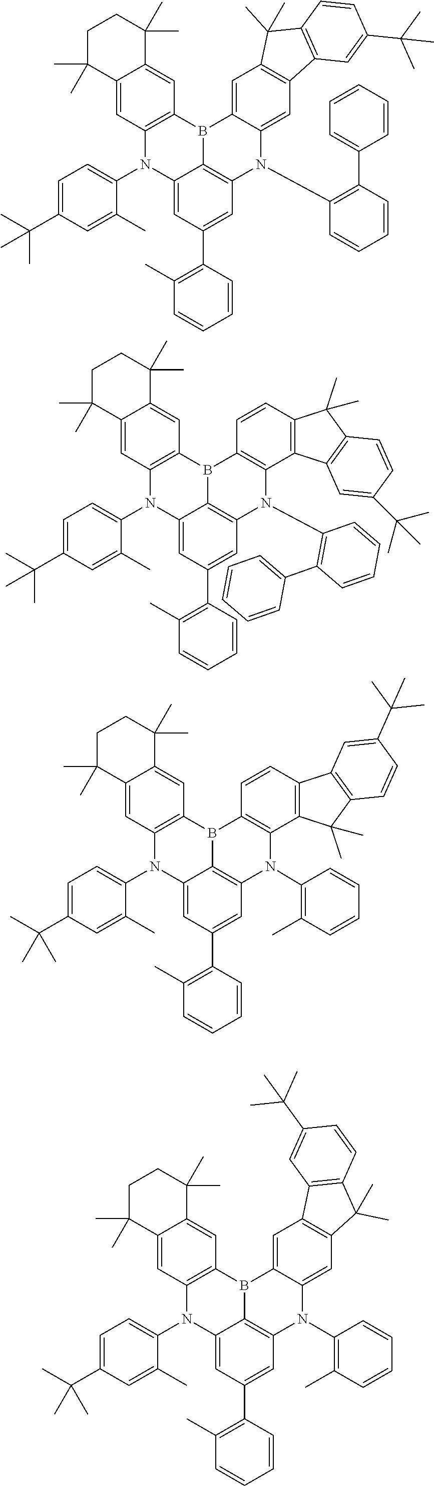

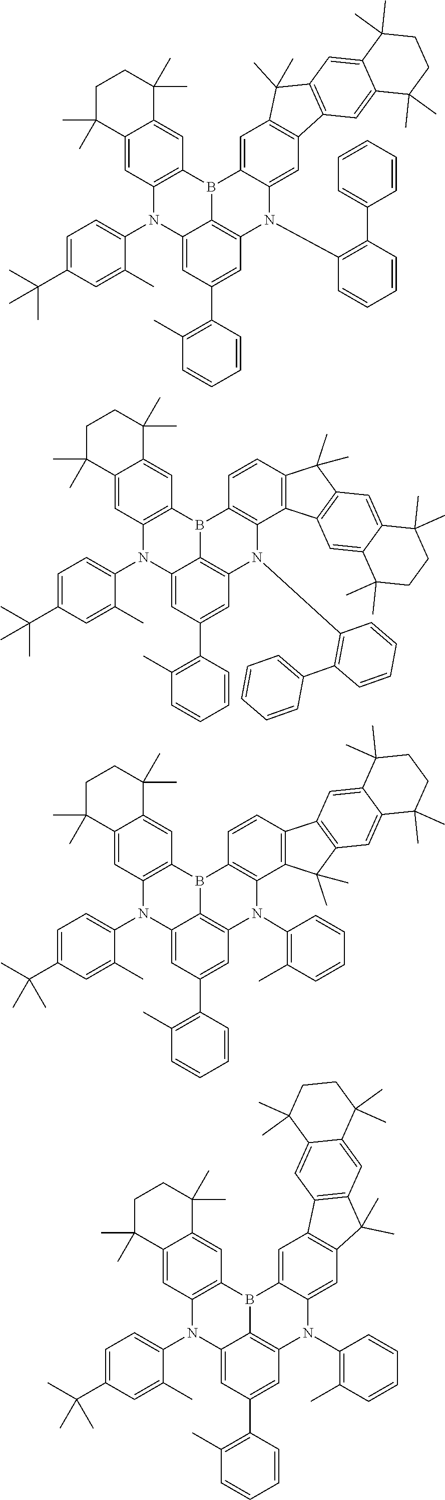

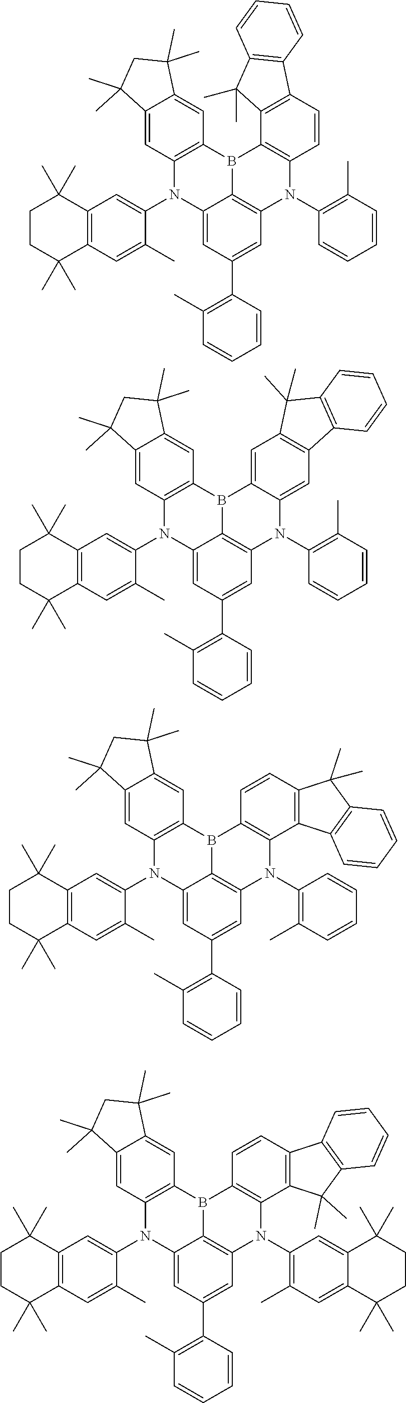

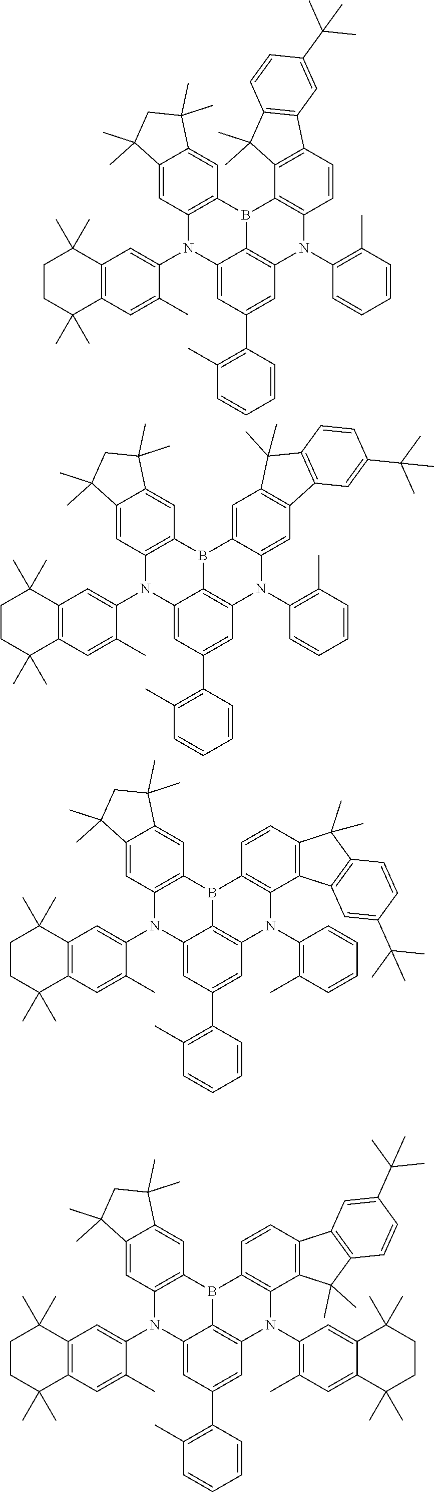

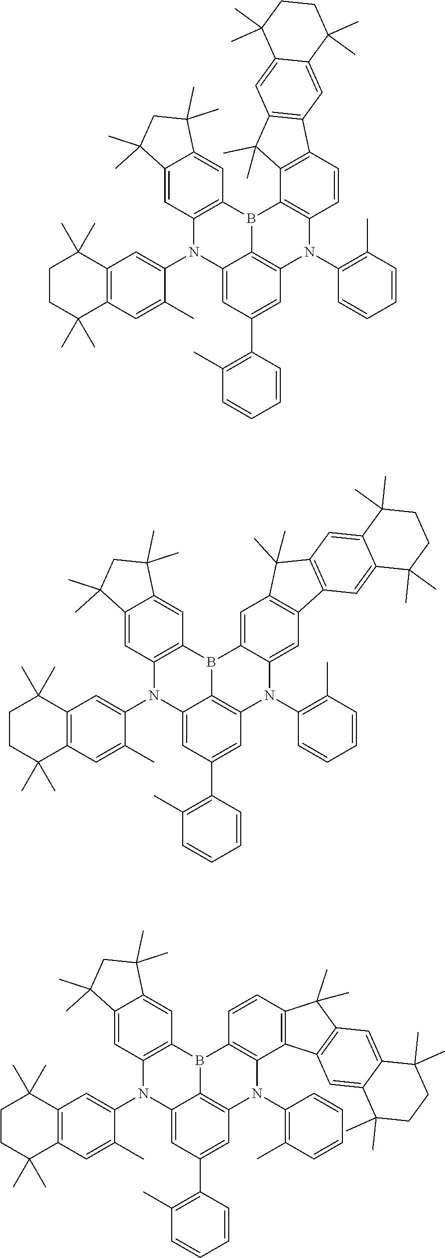 [SMILES: Cc1ccccc1-c1cc2c3c(c1)N(c1ccccc1C)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1ccccc1-c1cc2c3c(c1)N(c1cc4c(cc1C)C(C)(C)CCC4(C)C)c1cc4c(cc1B3c1cc3c(cc1N2c1ccccc1C)-c1cc2c(cc1C3(C)C)C(C)(C)CCC2(C)C)C(C)(C)CC4(C)C ; Cc1ccccc1-c1cc2c3c(c1)N(c1ccccc1C)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C]

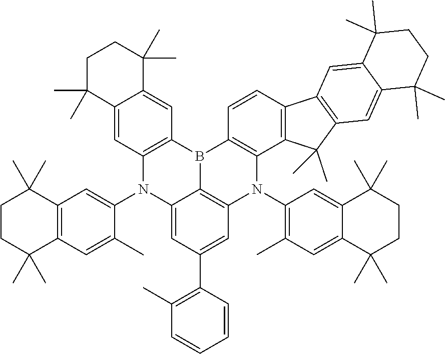 [SMILES: Cc1ccccc1-c1cc2c3c(c1)N(c1cc4c(cc1C)C(C)(C)CCC4(C)C)c1c(ccc4c1C(C)(C)c1cc5c(cc1-4)C(C)(C)CCC5(C)C)B3c1cc3c(cc1N2c1cc2c(cc1C)C(C)(C)CCC2(C)C)C(C)(C)CCC3(C)C]

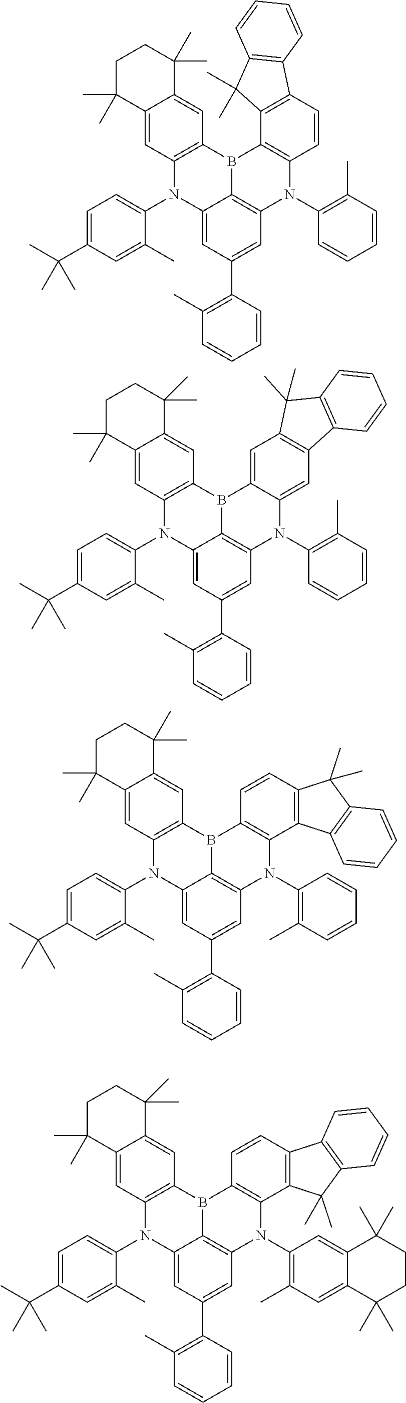

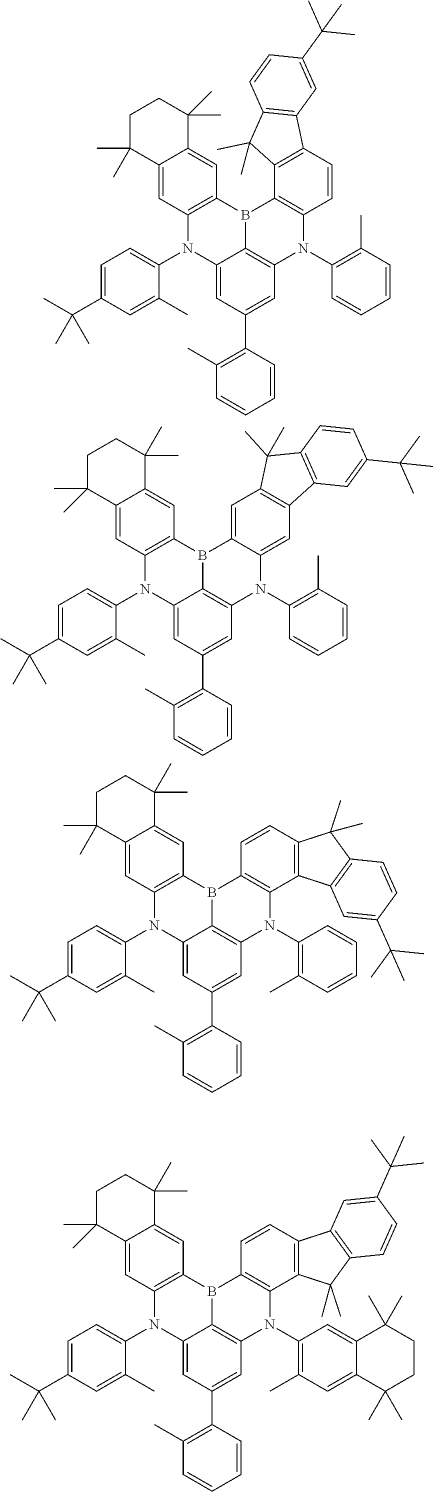

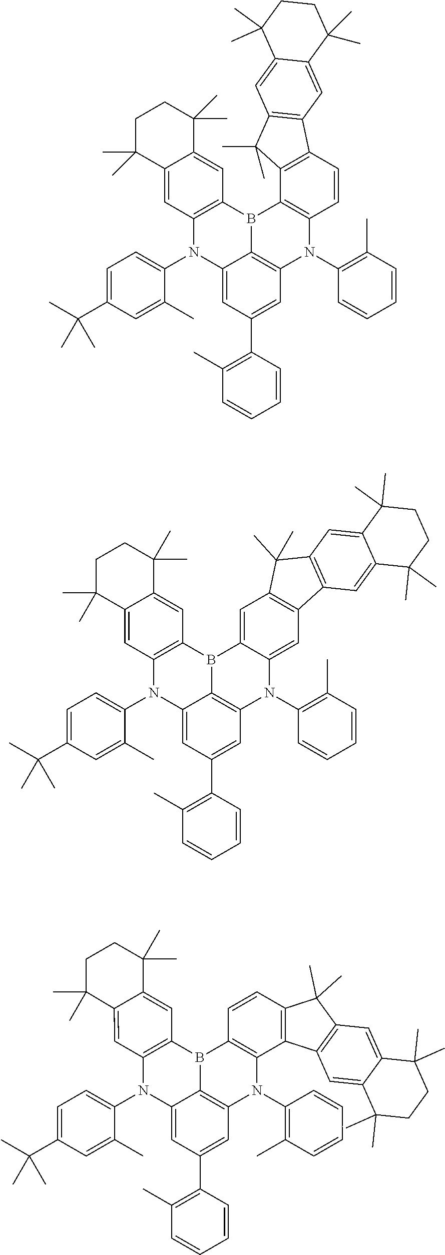

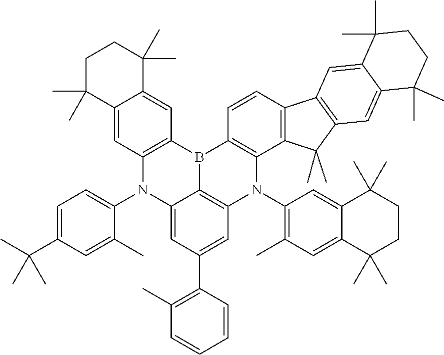 [SMILES: Cc1ccccc1-c1cc2c3c(c1)N(c1cc4c(cc1C)C(C)(C)CCC4(C)C)c1c(ccc4c1C(C)(C)c1cc5c(cc1-4)C(C)(C)CCC5(C)C)B3c1cc3c(cc1N2c1ccc(C(C)(C)C)cc1C)C(C)(C)CCC3(C)C]

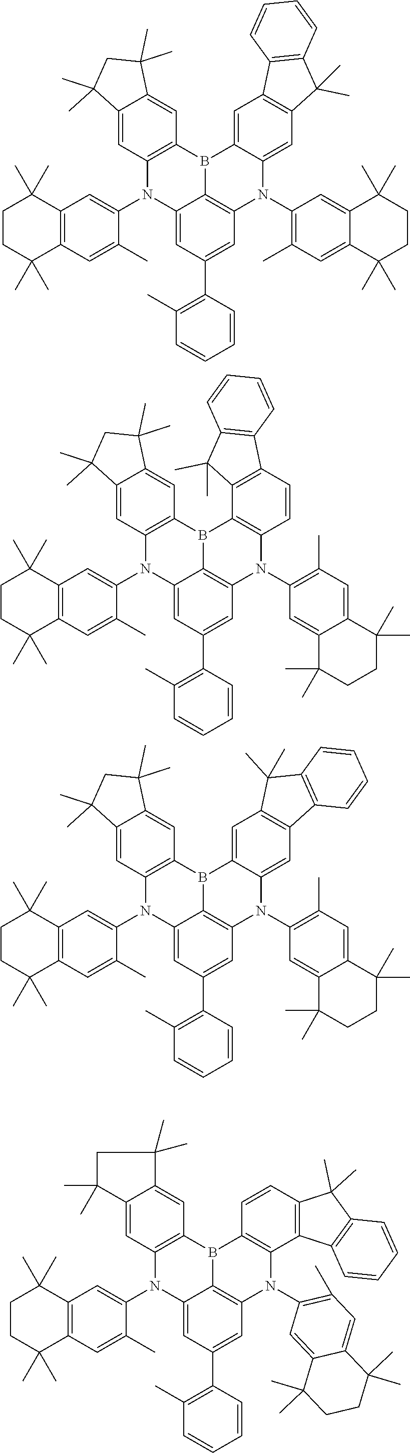

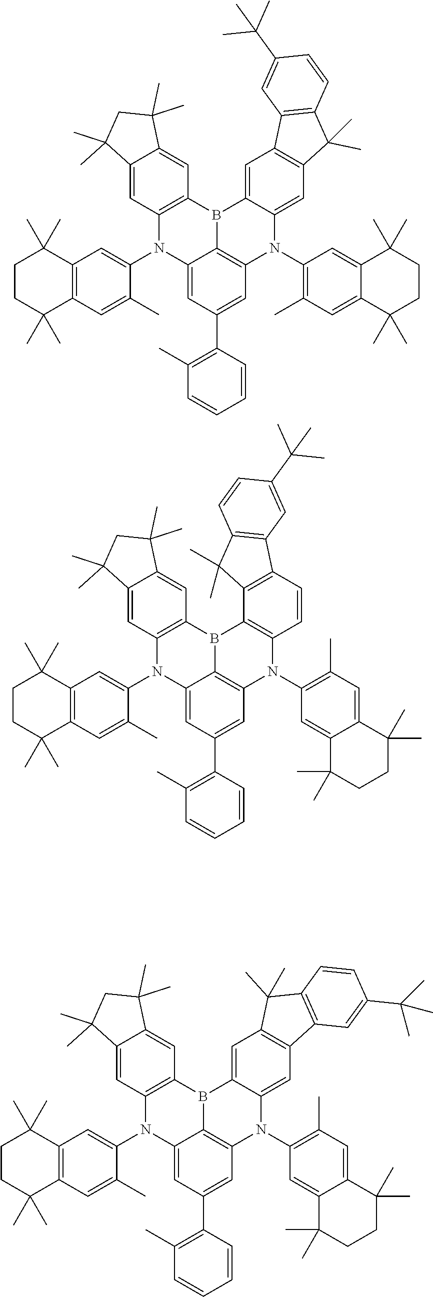

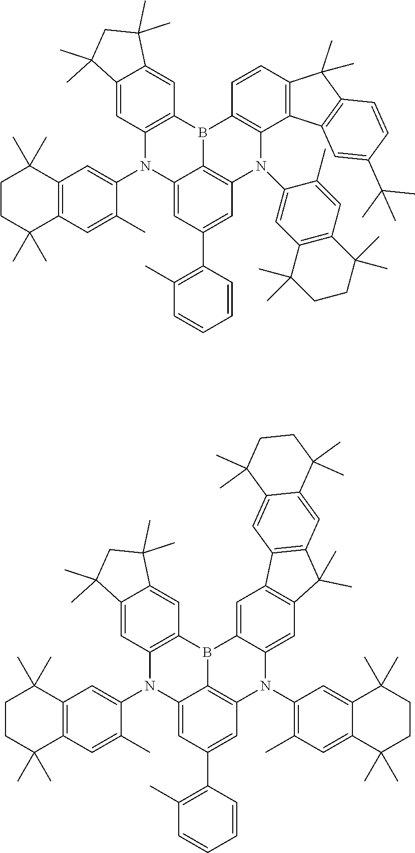 [SMILES: Cc1ccccc1-c1cc2c3c(c1)N(c1cc4c(cc1C)C(C)(C)CCC4(C)C)c1c(ccc4c1-c1cc(C(C)(C)C)ccc1C4(C)C)B3c1cc3c(cc1N2c1cc2c(cc1C)C(C)(C)CCC2(C)C)C(C)(C)CC3(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)C(C)(C)CC3(C)C)-c1cc2c(cc1C4(C)C)C(C)(C)CCC2(C)C]

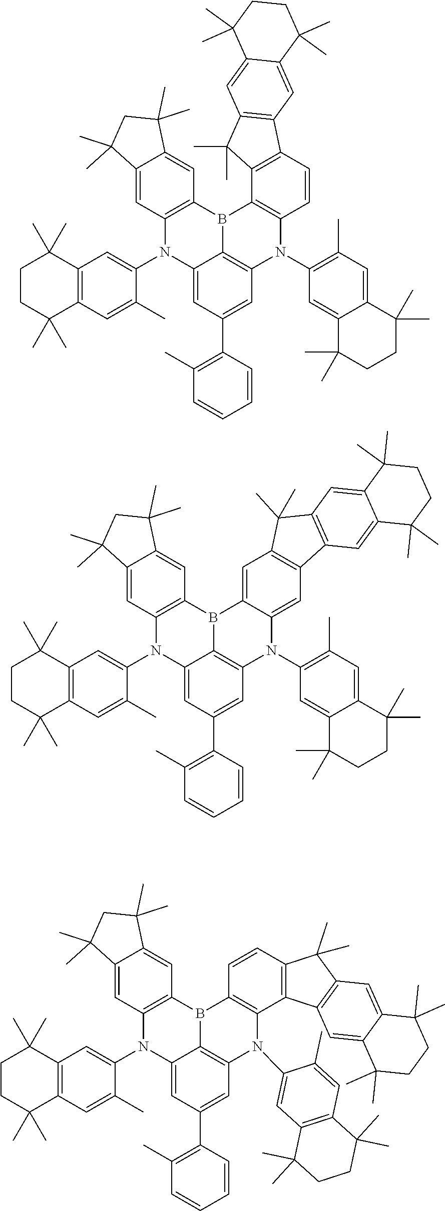 [SMILES: Cc1ccccc1-c1cc2c3c(c1)N(c1cc4c(cc1C)C(C)(C)CCC4(C)C)c1ccc4c(c1B3c1cc3c(cc1N2c1cc2c(cc1C)C(C)(C)CCC2(C)C)C(C)(C)CC3(C)C)C(C)(C)c1cc2c(cc1-4)C(C)(C)CCC2(C)C ; Cc1ccccc1-c1cc2c3c(c1)N(c1cc4c(cc1C)C(C)(C)CCC4(C)C)c1cc4c(cc1B3c1cc3c(cc1N2c1cc2c(cc1C)C(C)(C)CCC2(C)C)-c1cc2c(cc1C3(C)C)C(C)(C)CCC2(C)C)C(C)(C)CC4(C)C ; Cc1ccccc1-c1cc2c3c(c1)N(c1cc4c(cc1C)C(C)(C)CCC4(C)C)c1c(ccc4c1-c1cc5c(cc1C4(C)C)C(C)(C)CCC5(C)C)B3c1cc3c(cc1N2c1cc2c(cc1C)C(C)(C)CCC2(C)C)C(C)(C)CC3(C)C]

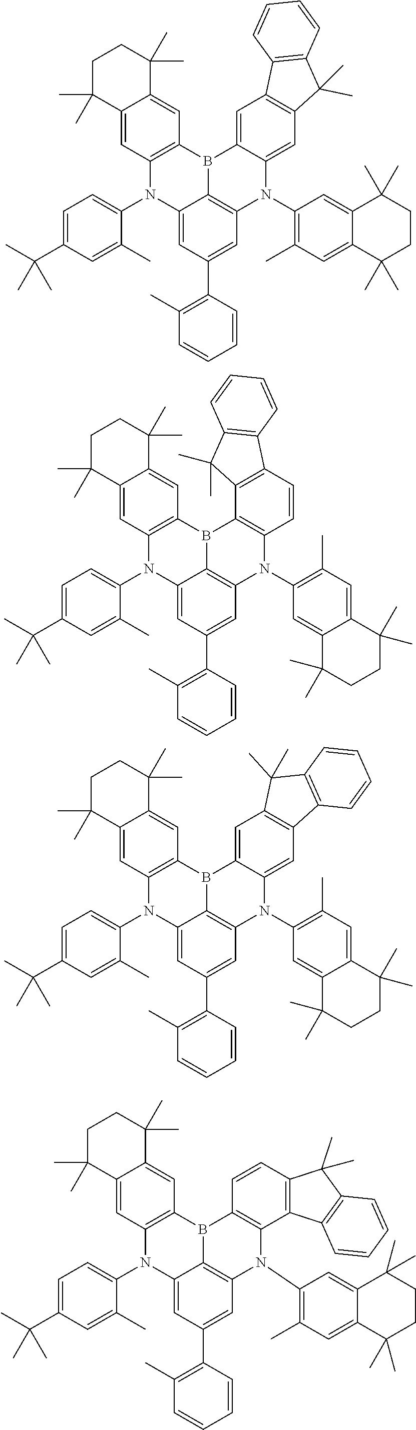

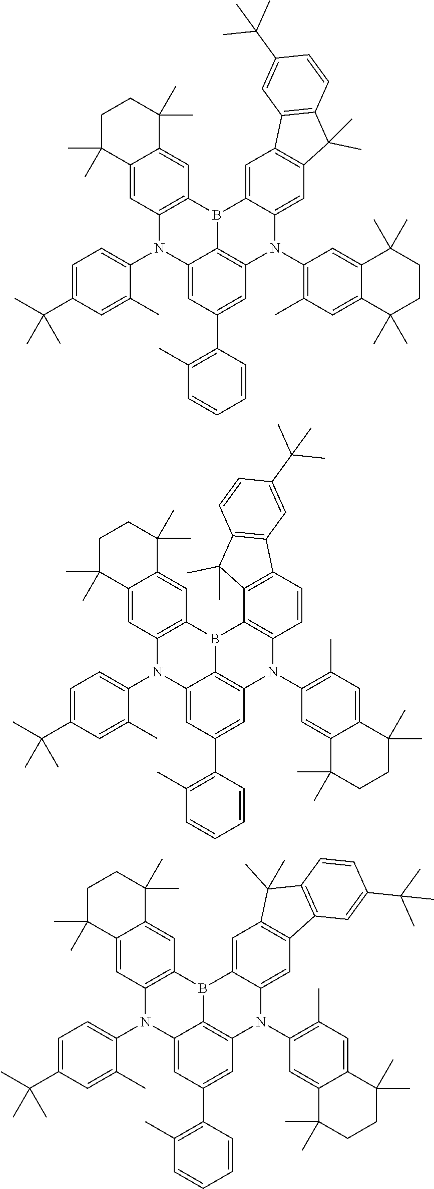

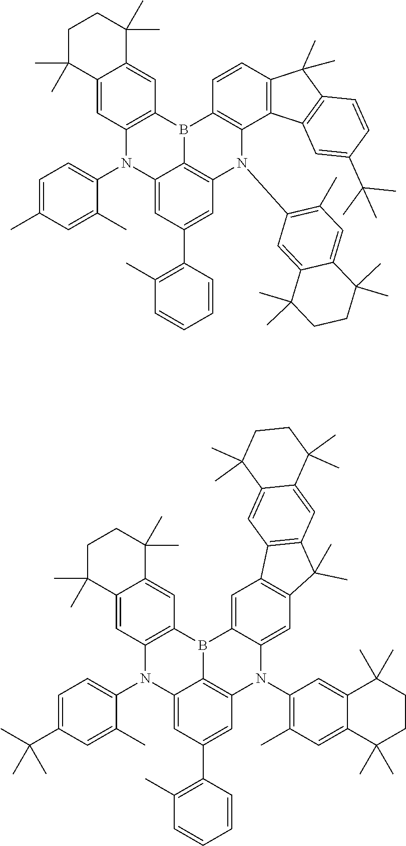

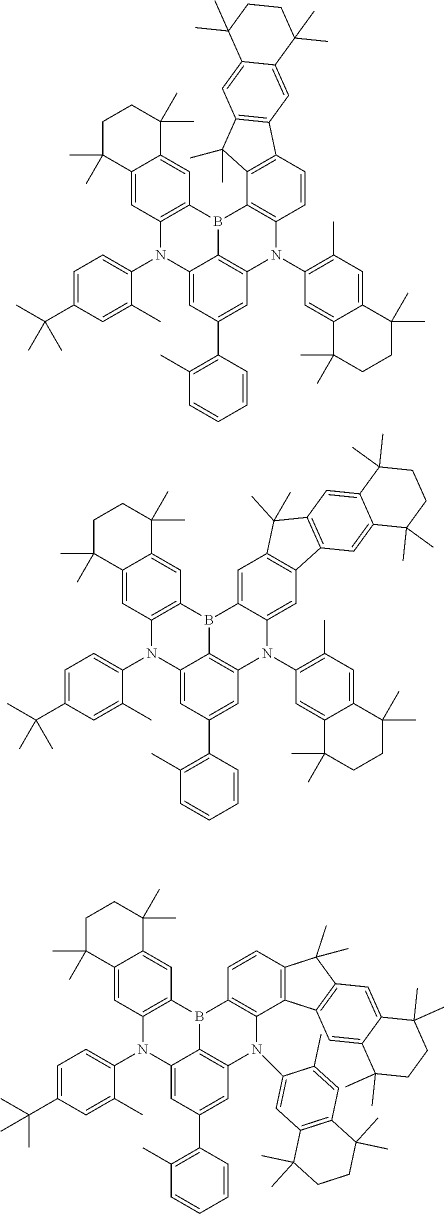

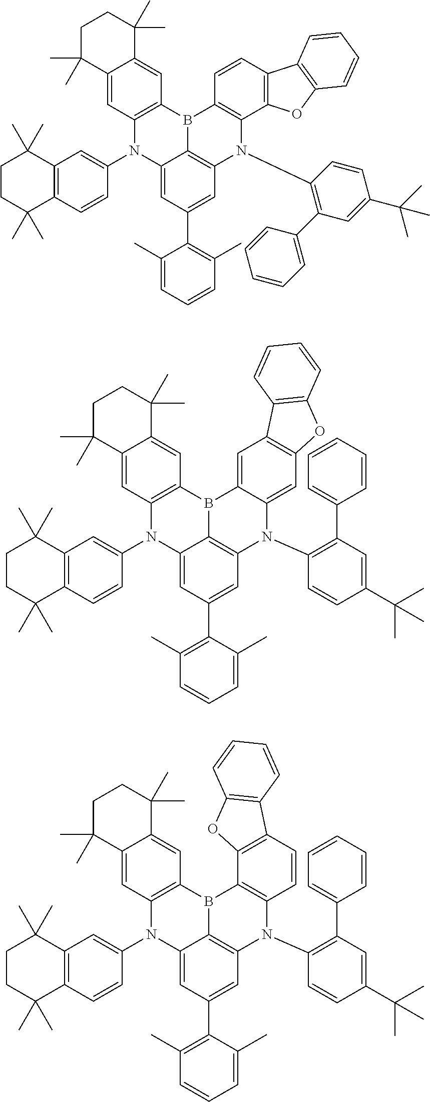

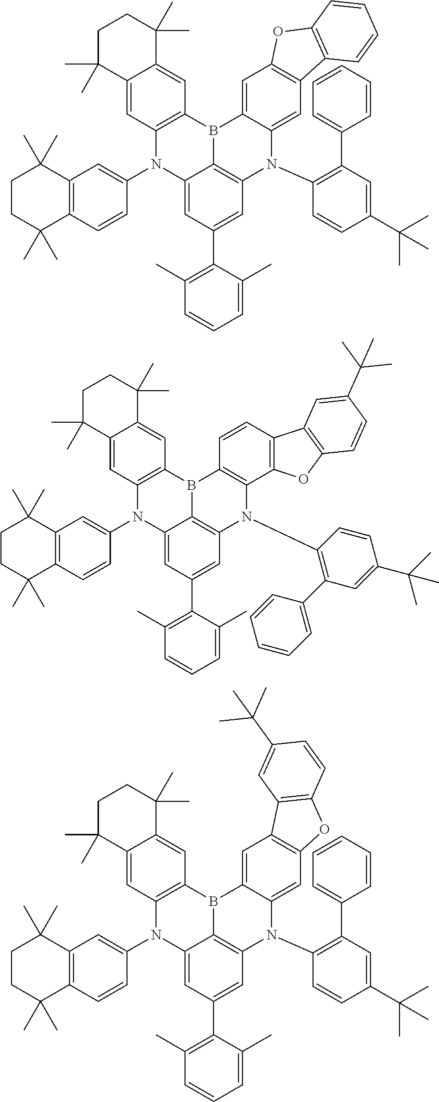

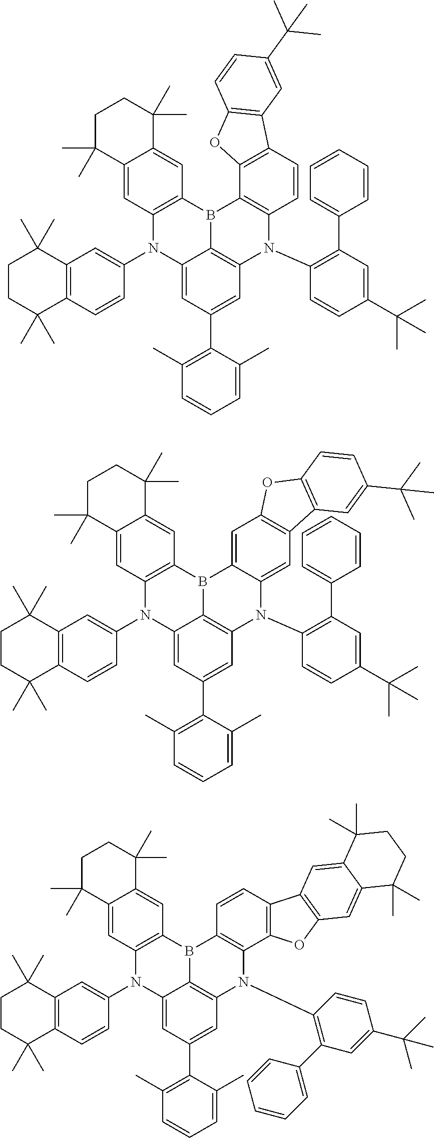 [SMILES: Cc1cccc(C)c1-c1cc2c3c(c1)N(c1ccc(C(C)(C)C)cc1-c1ccccc1)c1ccc4c(oc5ccc(C(C)(C)C)cc54)c1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)oc1ccc(C(C)(C)C)cc14 ; Cc1cccc(C)c1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C]

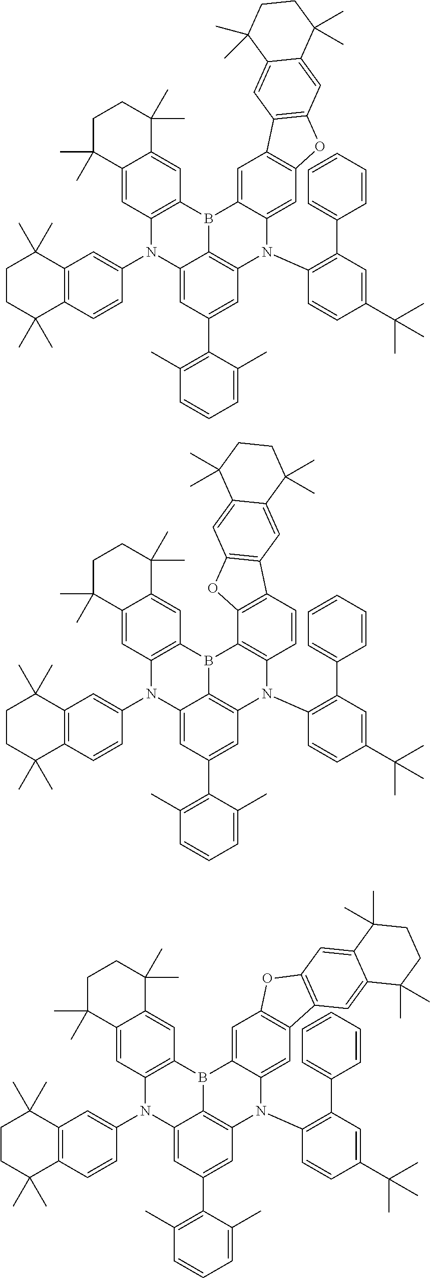

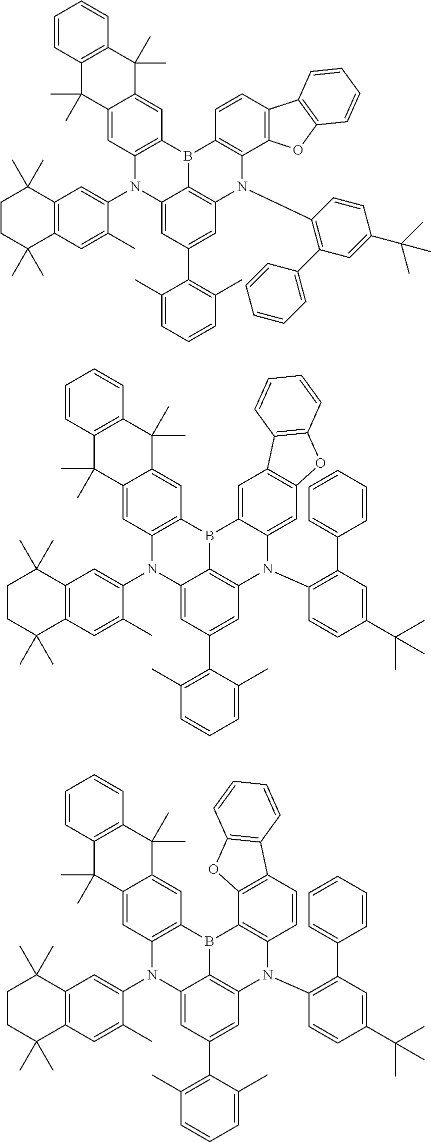 [SMILES: Cc1cc2c(cc1N1c3cc4c(cc3B3c5ccc6c(oc7ccccc76)c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)oc1ccccc16)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(oc6ccccc65)c13)C(C)(C)c1ccccc1C4(C)C)C(C)(C)CCC2(C)C]

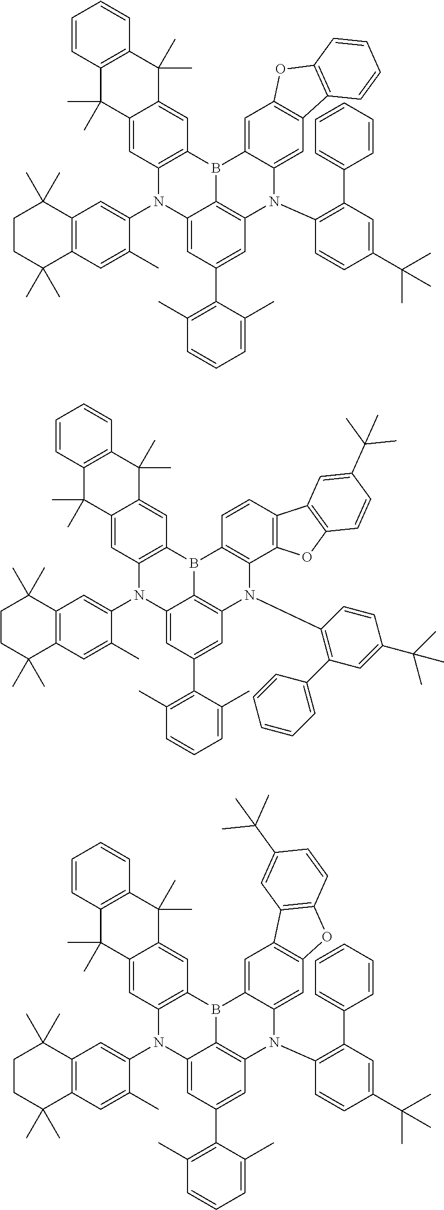 [SMILES: Cc1cc2c(cc1N1c3cc4c(cc3B3c5cc6oc7ccccc7c6cc5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)oc1ccc(C(C)(C)C)cc16)C(C)(C)c1ccccc1C4(C)C)C(C)(C)CCC2(C)C]

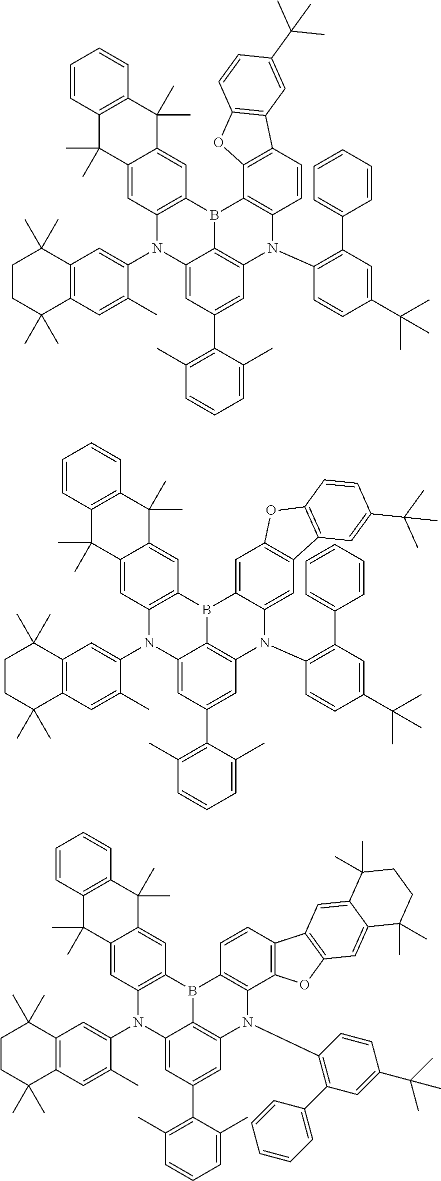 [SMILES: Cc1cc2c(cc1N1c3cc4c(cc3B3c5c1cc(-c1c(C)cccc1C)cc5N(c1ccc(C(C)(C)C)cc1-c1ccccc1)c1ccc5c(oc6ccc(C(C)(C)C)cc65)c13)C(C)(C)c1ccccc1C4(C)C)C(C)(C)CCC2(C)C ; Cc1cc2c(cc1N1c3cc4c(cc3B3c5cc6oc7ccc(C(C)(C)C)cc7c6cc5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccc(C(C)(C)C)cc5-c5ccccc5)c5cc(-c6c(C)cccc6C)cc1c53)C(C)(C)c1ccccc1C4(C)C)C(C)(C)CCC2(C)C]

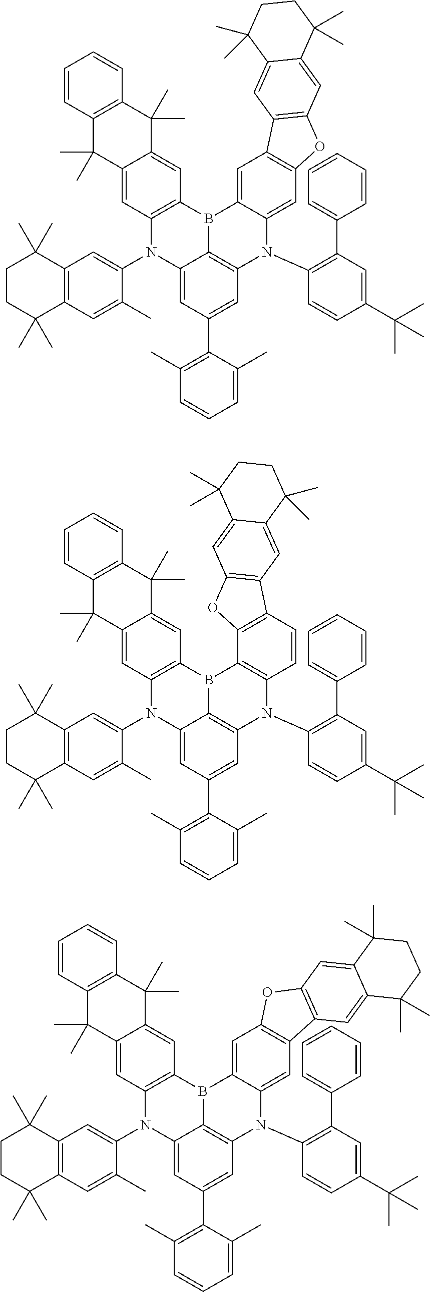 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5ccc(C(C)(C)C)cc5-c5ccccc5)c5cc(-c6c(C)cccc6C)cc1c53)C(C)(C)CCC8(C)C)C(C)(C)c1ccccc1C4(C)C)C(C)(C)CCC2(C)C]

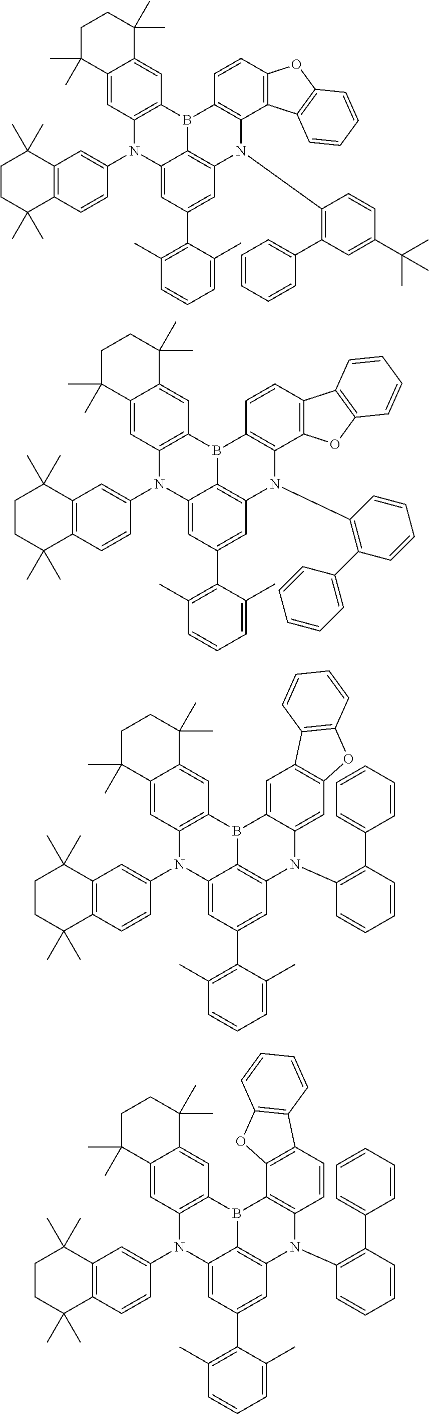

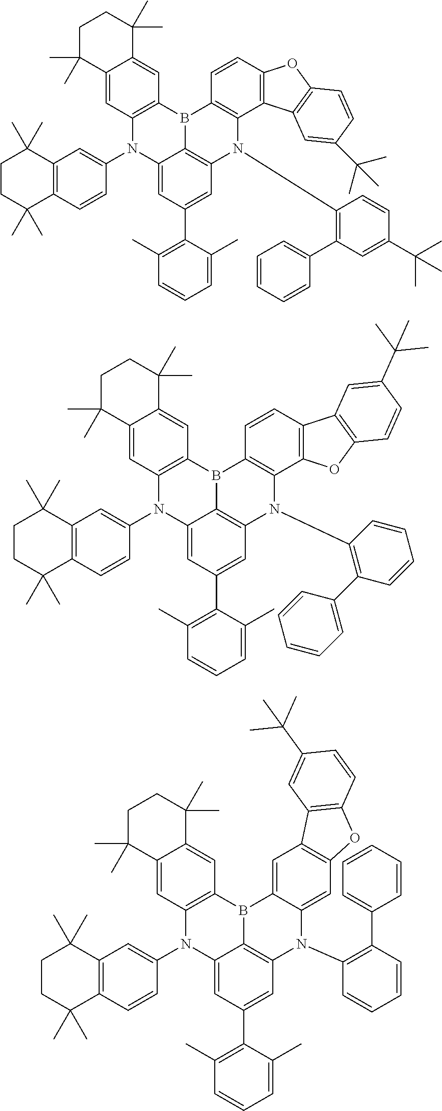

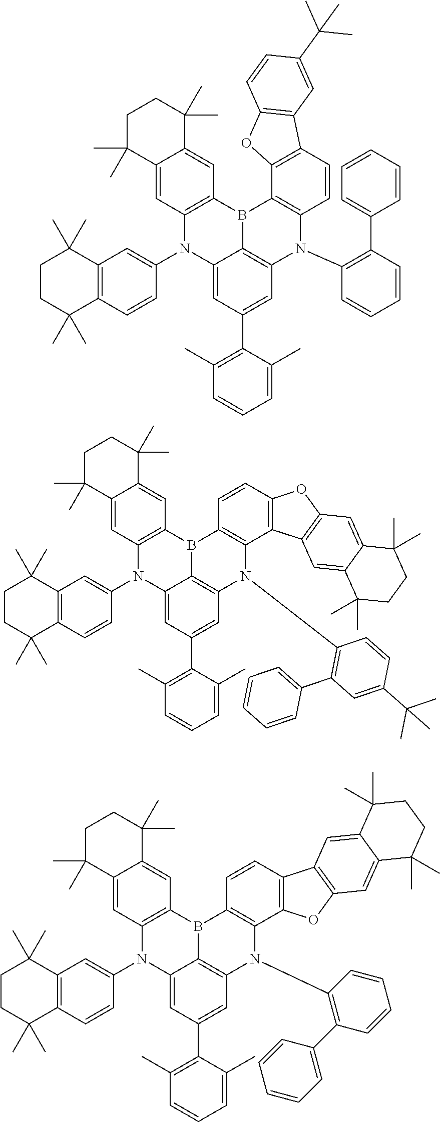

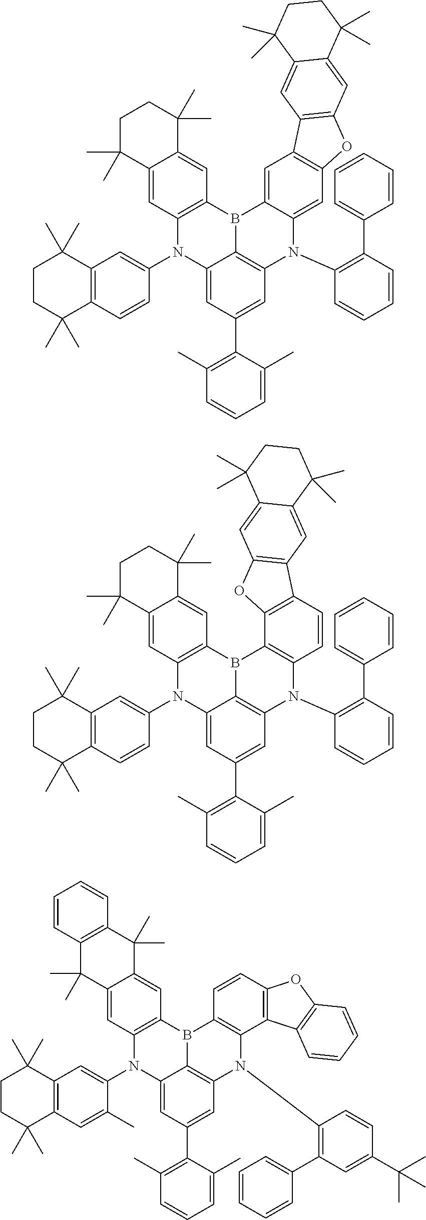

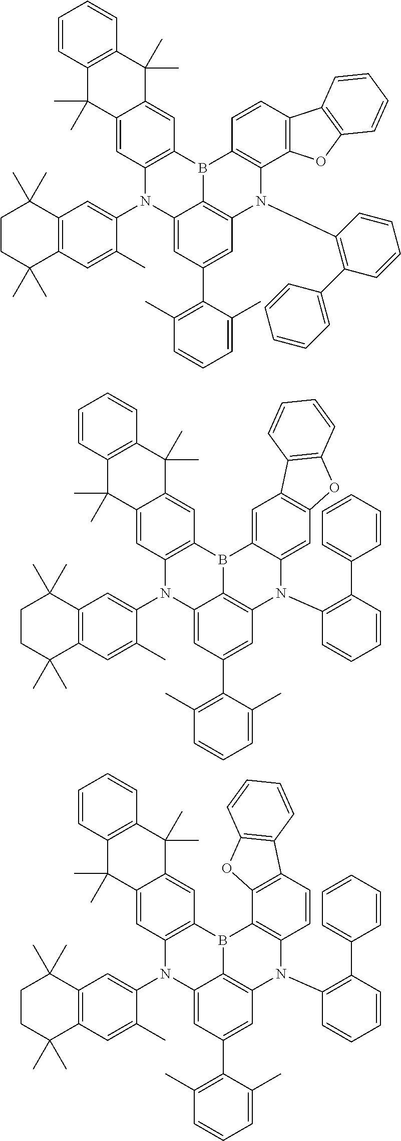

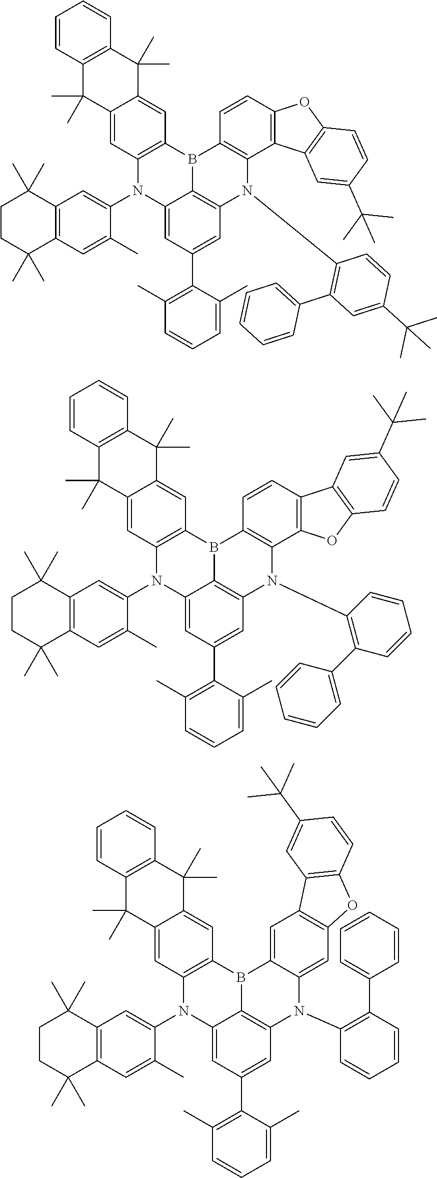

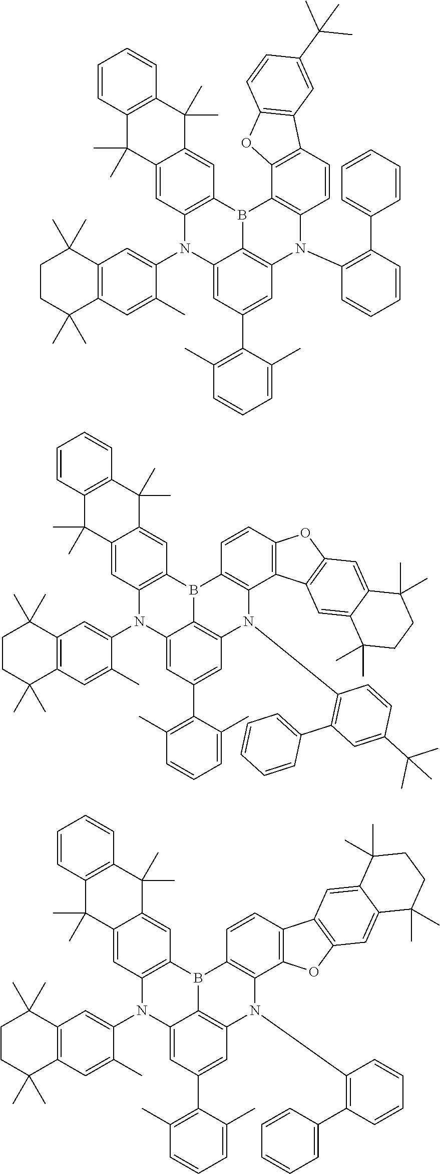

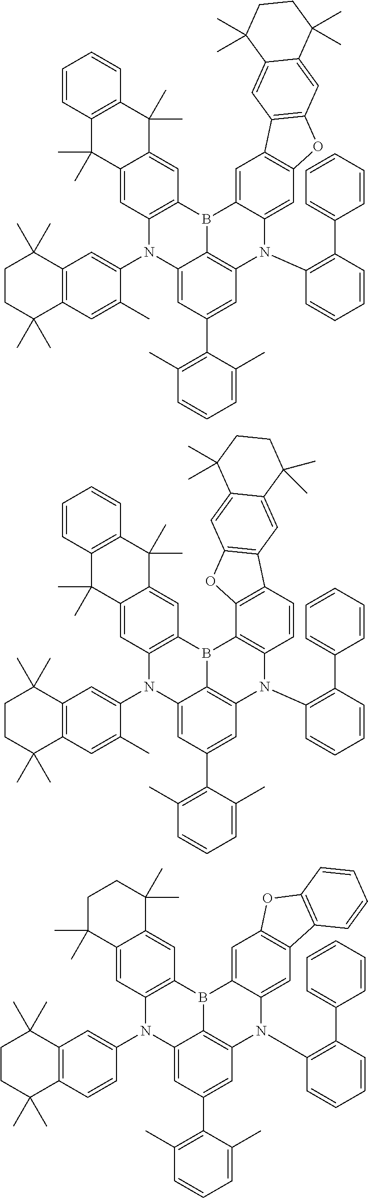

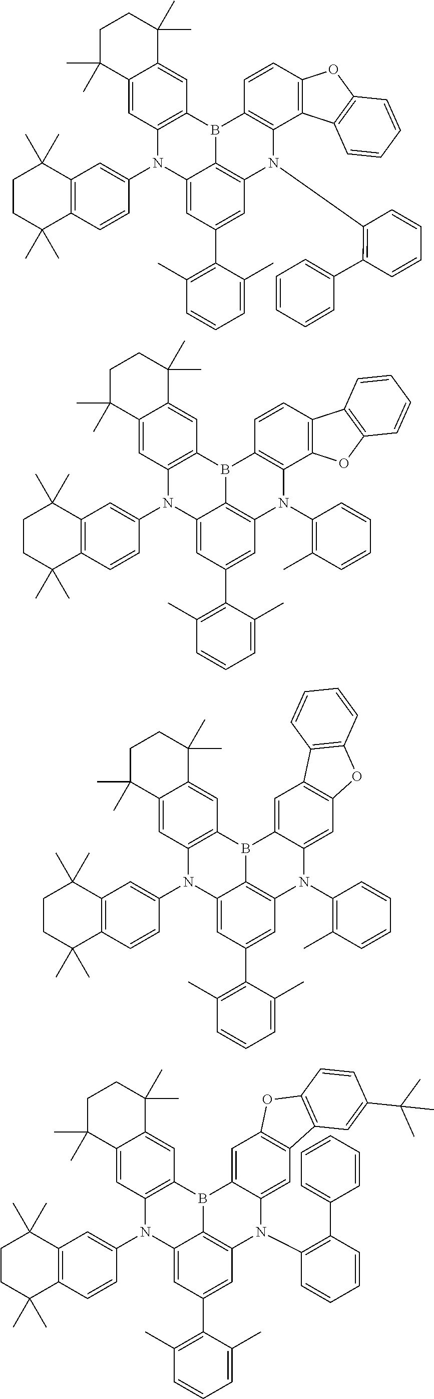

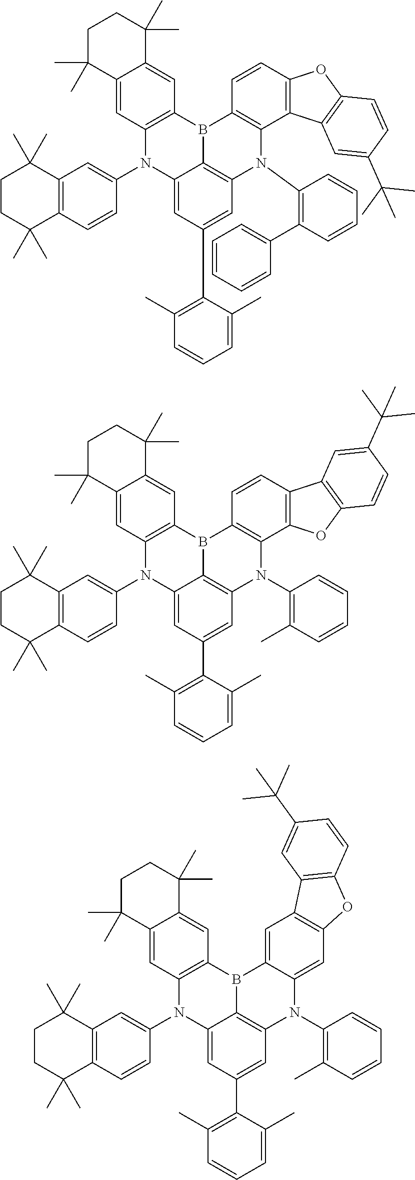 [SMILES: Cc1cccc(C)c1-c1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)CCC2(C)C)C(C)(C)CCC3(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)CCC5(C)C)c3cc(-c5c(C)cccc5C)cc1c32)C(C)(C)CCC4(C)C]

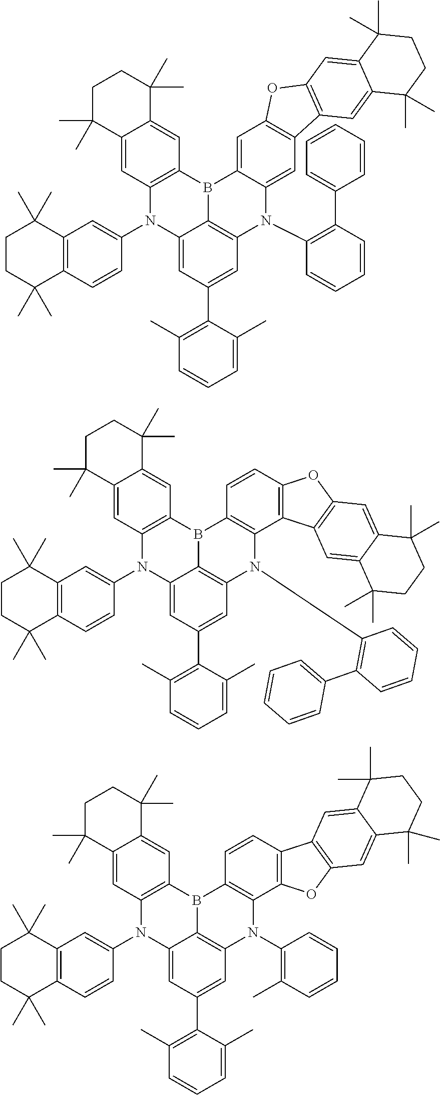

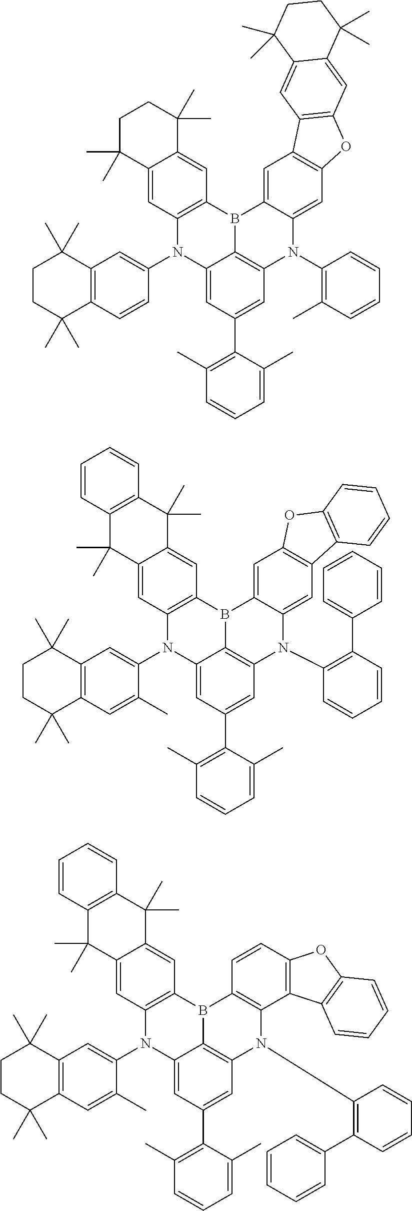 [SMILES: Cc1ccccc1N1c2cc3oc4cc5c(cc4c3cc2B2c3cc4c(cc3N(c3ccc6c(c3)C(C)(C)CCC6(C)C)c3cc(-c6c(C)cccc6C)cc1c32)C(C)(C)CCC4(C)C)C(C)(C)CCC5(C)C ; Cc1cc2c(cc1N1c3cc4c(cc3B3c5cc6oc7ccccc7c6cc5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(-c6c(C)cccc6C)cc1c53)C(C)(C)c1ccccc1C4(C)C)C(C)(C)CCC2(C)C]

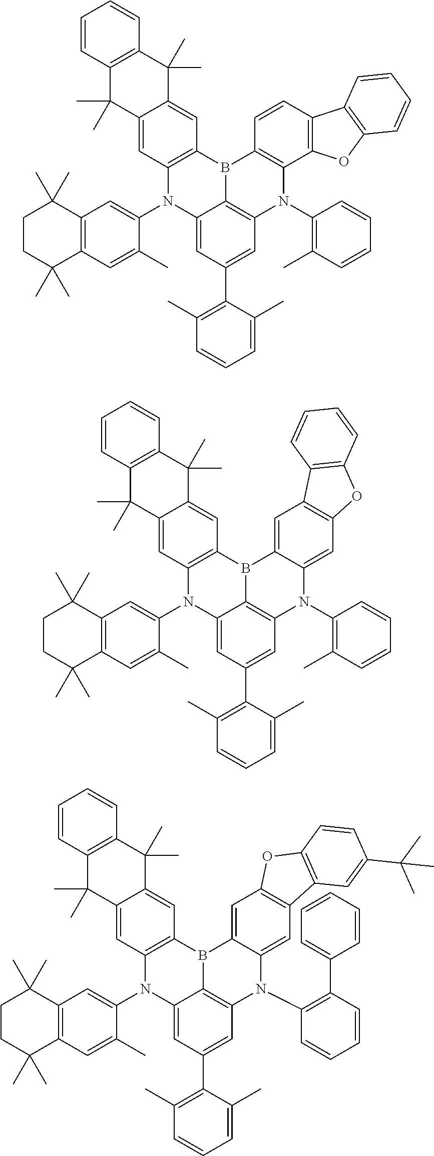 [SMILES: Cc1cc2c(cc1N1c3cc4c(cc3B3c5ccc6c(oc7ccccc76)c5N(c5ccccc5C)c5cc(-c6c(C)cccc6C)cc1c53)C(C)(C)c1ccccc1C4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(-c5c(C)cccc5C)cc1c32)C(C)(C)c1ccccc1C4(C)C ; Cc1cc2c(cc1N1c3cc4c(cc3B3c5cc6oc7ccc(C(C)(C)C)cc7c6cc5N(c5ccccc5-c5ccccc5)c5cc(-c6c(C)cccc6C)cc1c53)C(C)(C)c1ccccc1C4(C)C)C(C)(C)CCC2(C)C]

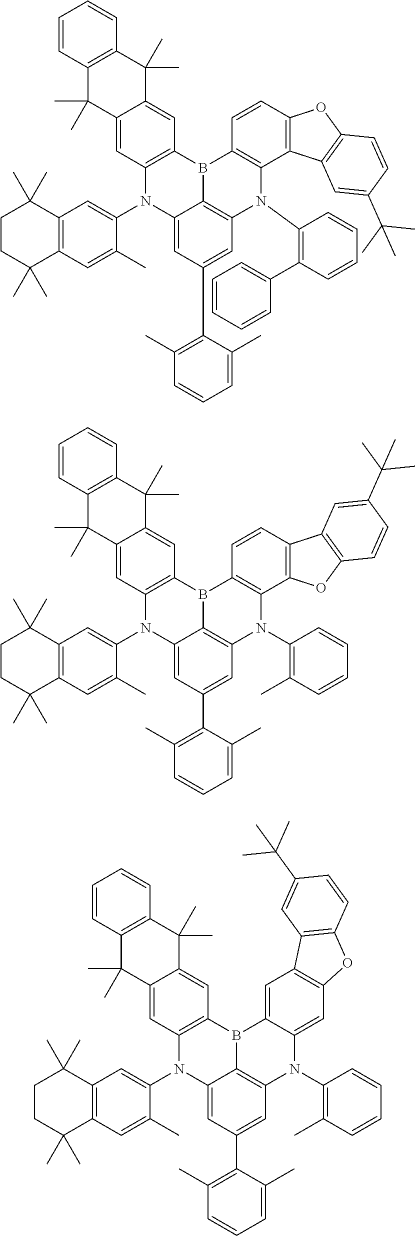 [SMILES: Cc1cc2c(cc1N1c3cc4c(cc3B3c5ccc6oc7ccc(C(C)(C)C)cc7c6c5N(c5ccccc5-c5ccccc5)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5ccccc5C)c5cc(-c6c(C)cccc6C)cc1c53)C(C)(C)c1ccccc1C4(C)C)C(C)(C)CCC2(C)C ; Cc1ccccc1N1c2cc3oc4ccc(C(C)(C)C)cc4c3cc2B2c3cc4c(cc3N(c3cc5c(cc3C)C(C)(C)CCC5(C)C)c3cc(-c5c(C)cccc5C)cc1c32)C(C)(C)c1ccccc1C4(C)C]

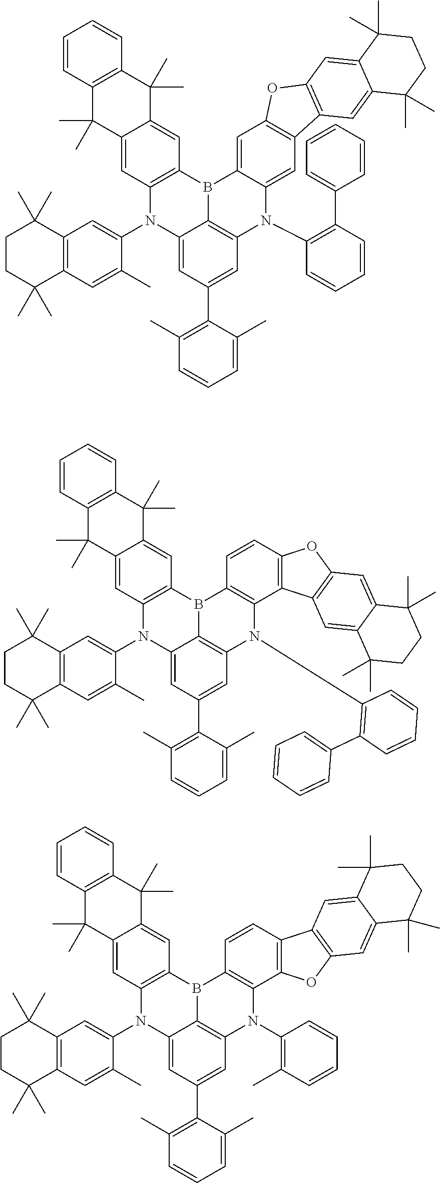 [SMILES: Cc1cc2c(cc1N1c3cc4c(cc3B3c5cc6oc7cc8c(cc7c6cc5N(c5ccccc5-c5ccccc5)c5cc(-c6c(C)cccc6C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5ccccc5-c5ccccc5)c5cc(-c6c(C)cccc6C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5C)c5cc(-c6c(C)cccc6C)cc1c53)C(C)(C)c1ccccc1C4(C)C)C(C)(C)CCC2(C)C]

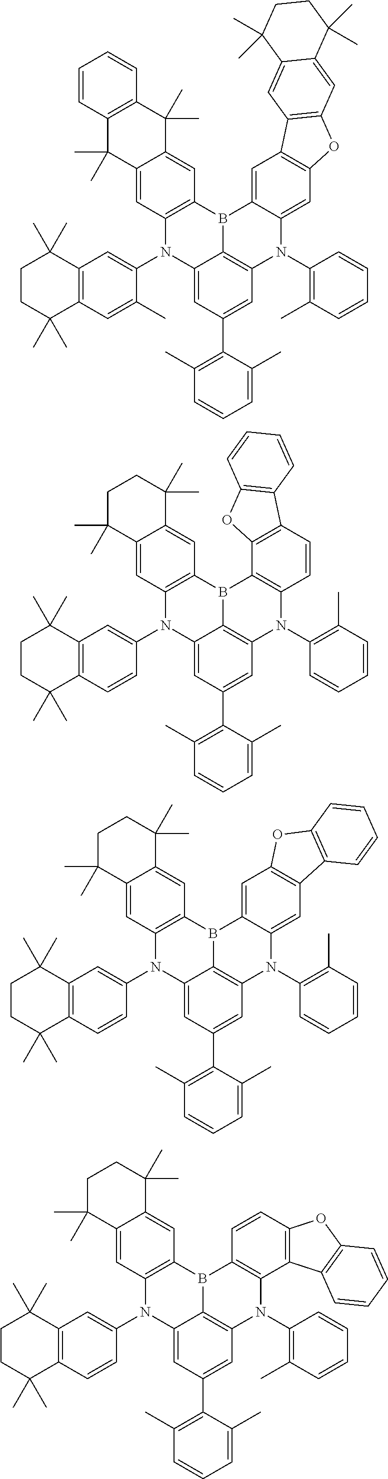

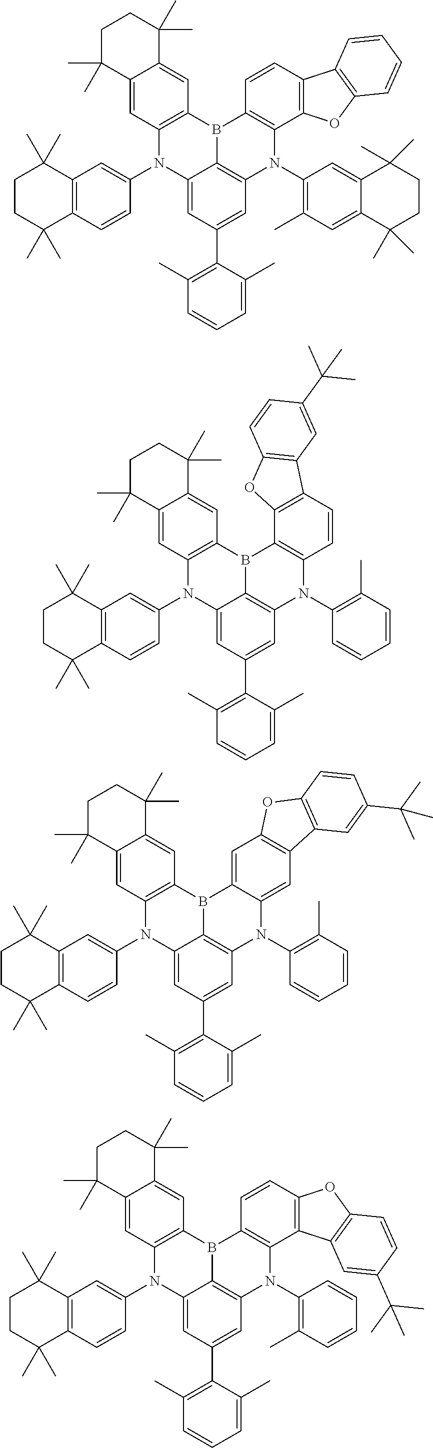

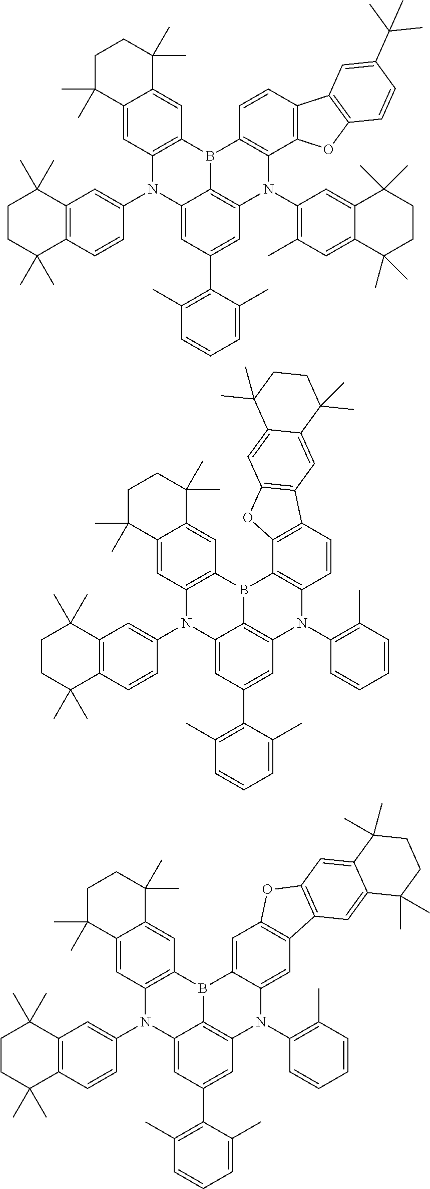

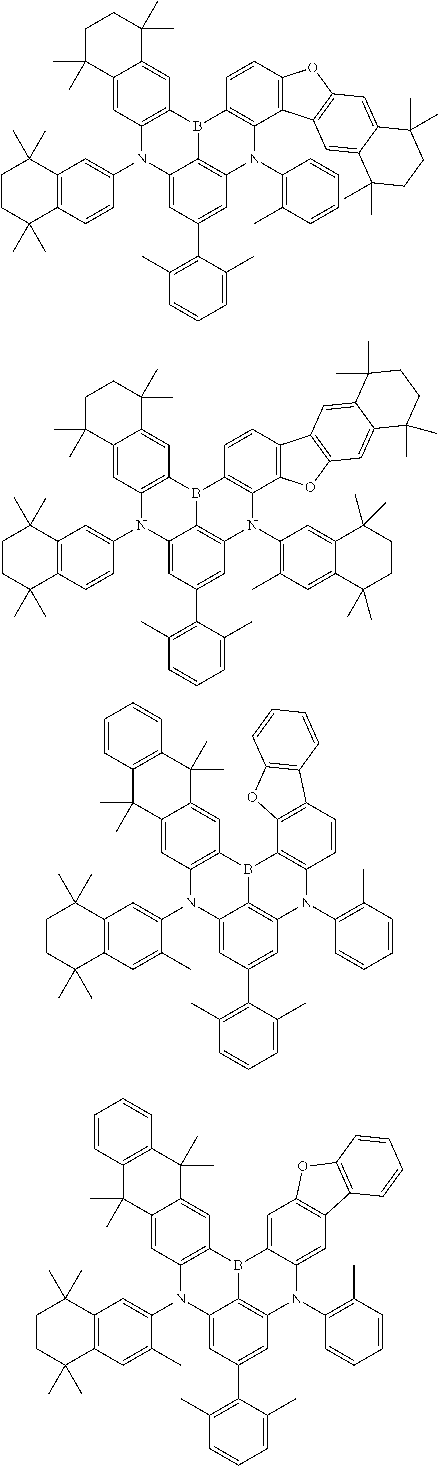

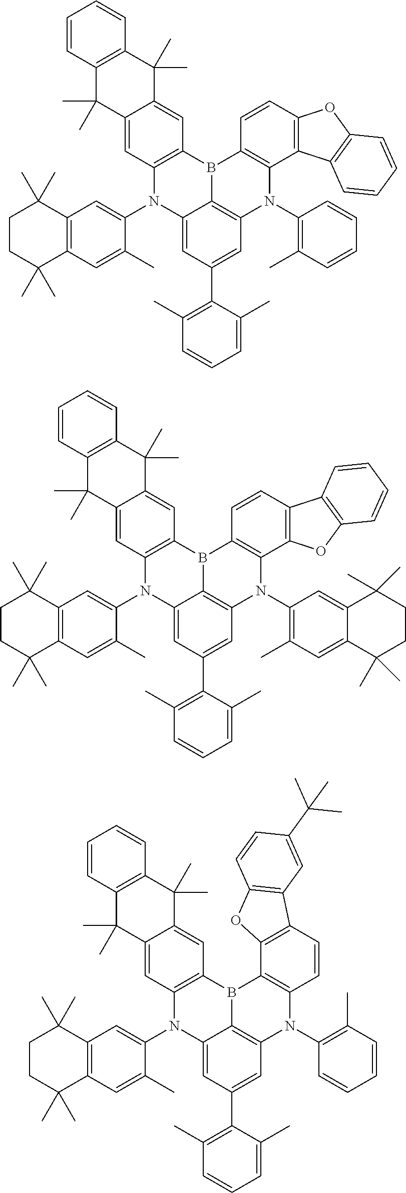 [SMILES: Cc1cc2c(cc1N1c3cc4c(cc3B3c5ccc6oc7ccccc7c6c5N(c5ccccc5C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(oc6ccc(C(C)(C)C)cc65)c13)C(C)(C)c1ccccc1C4(C)C)C(C)(C)CCC2(C)C]

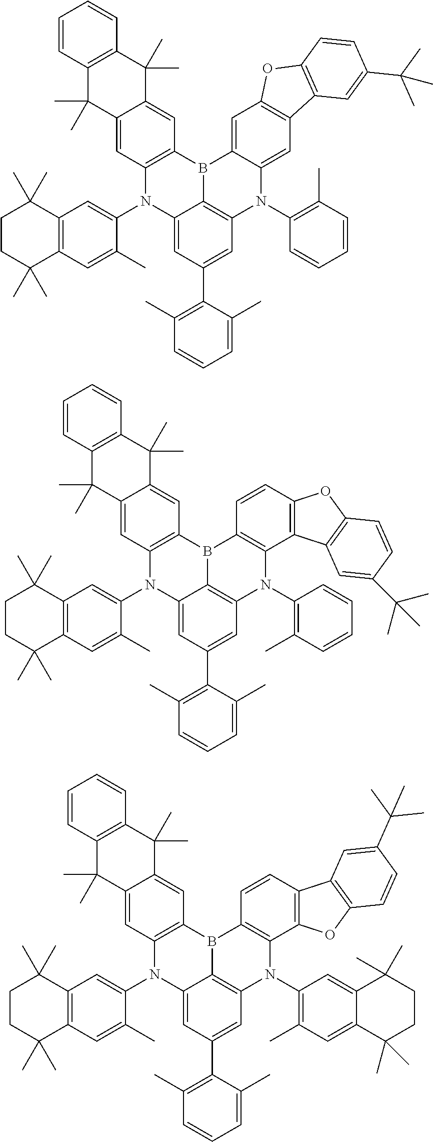 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)oc1ccc(C(C)(C)C)cc13 ; Cc1cc2c(cc1N1c3cc4c(cc3B3c5ccc6oc7ccc(C(C)(C)C)cc7c6c5N(c5ccccc5C)c5cc(-c6c(C)cccc6C)cc1c53)C(C)(C)c1ccccc1C4(C)C)C(C)(C)CCC2(C)C ; Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(-c6c(C)cccc6C)cc1c53)C(C)(C)c1ccccc1C4(C)C)C(C)(C)CCC2(C)C]

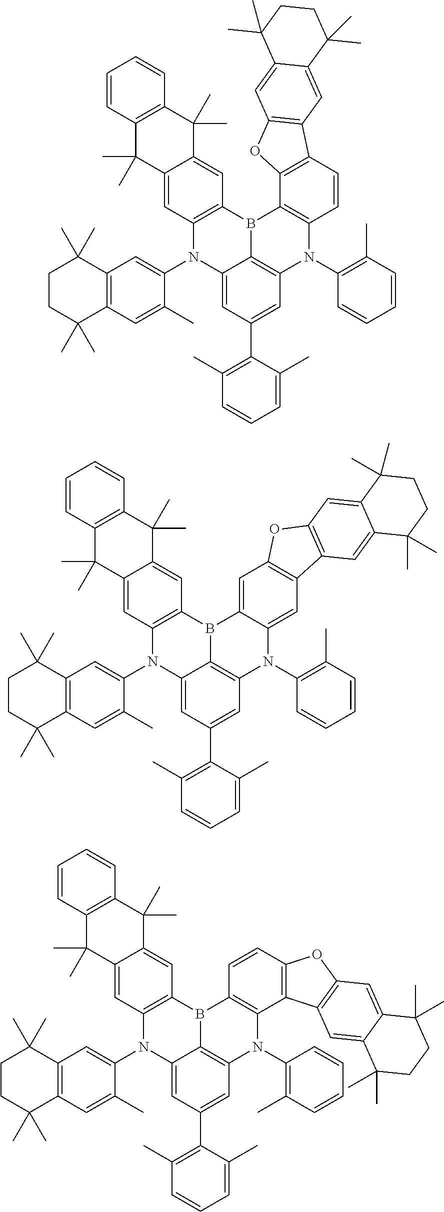 [SMILES: Cc1cc2c(cc1N1c3cc4c(cc3B3c5c1cc(-c1c(C)cccc1C)cc5N(c1ccccc1C)c1ccc5c(oc6cc7c(cc65)C(C)(C)CCC7(C)C)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)oc1cc2c(cc13)C(C)(C)CCC2(C)C ; Cc1cc2c(cc1N1c3cc4c(cc3B3c5ccc6oc7cc8c(cc7c6c5N(c5ccccc5C)c5cc(-c6c(C)cccc6C)cc1c53)C(C)(C)CCC8(C)C)C(C)(C)c1ccccc1C4(C)C)C(C)(C)CCC2(C)C]

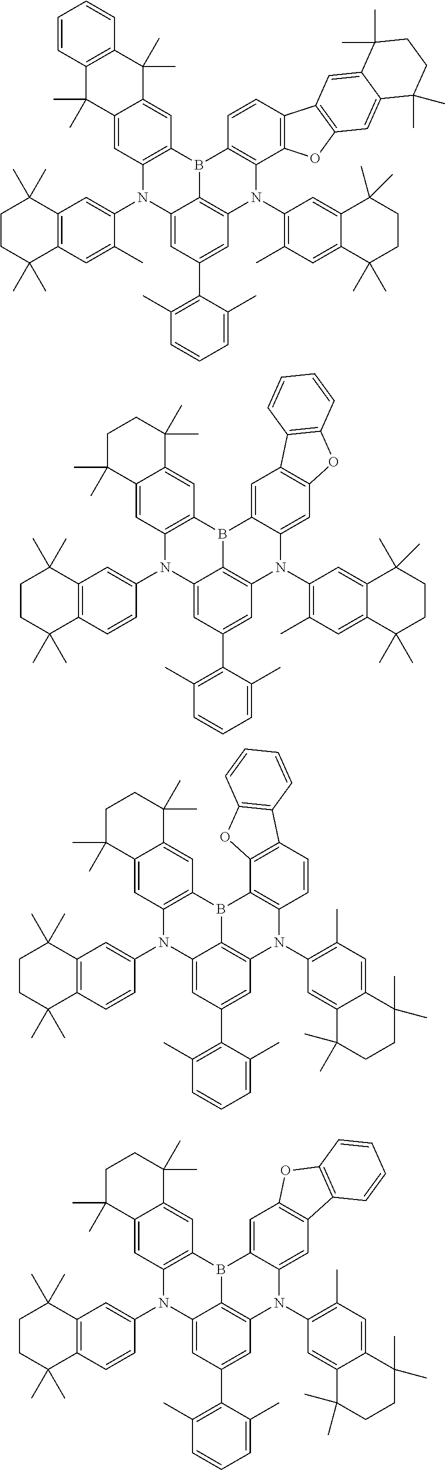

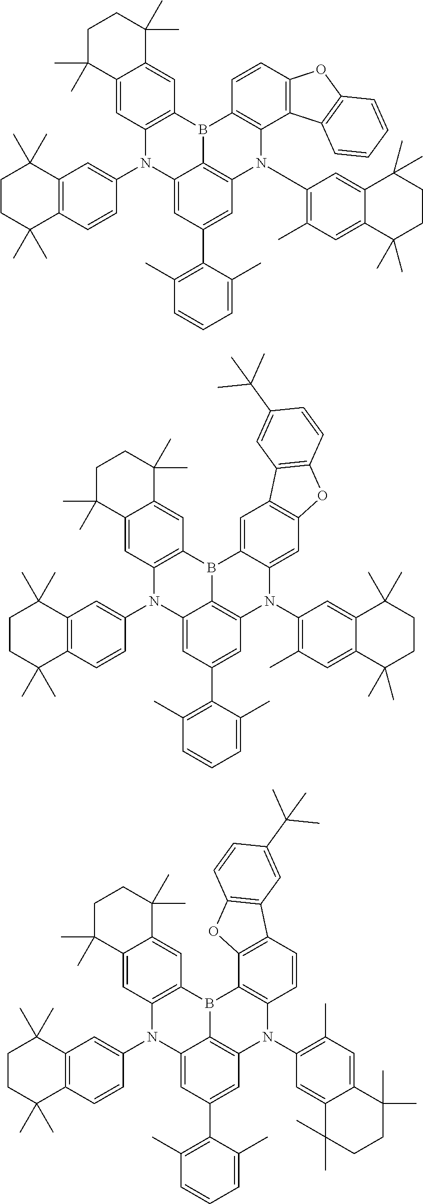

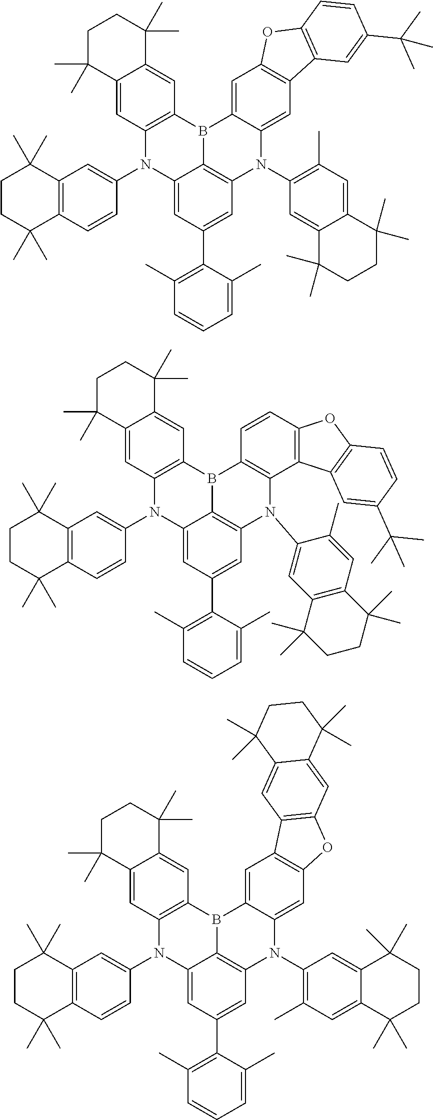

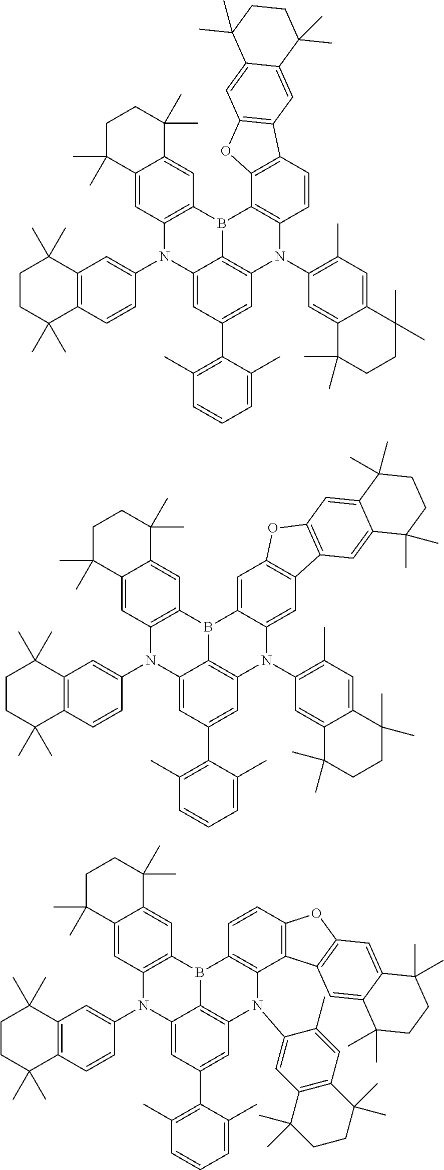

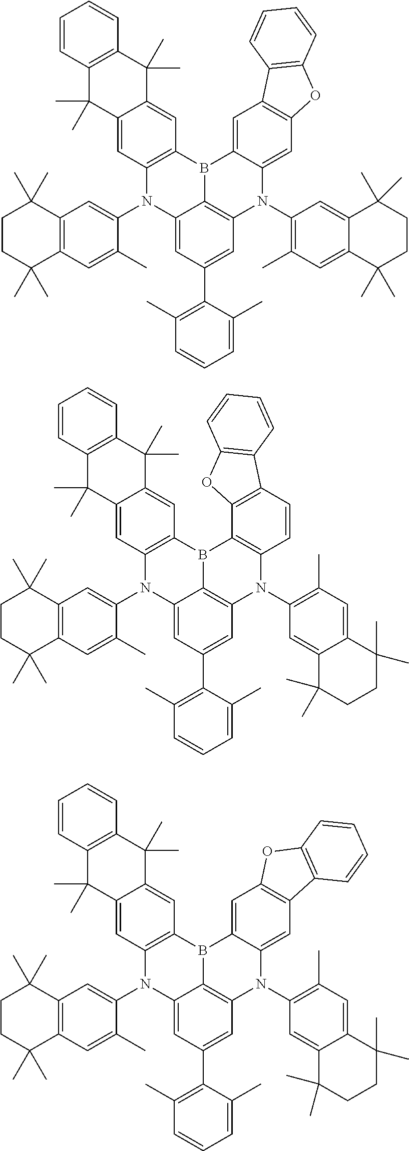

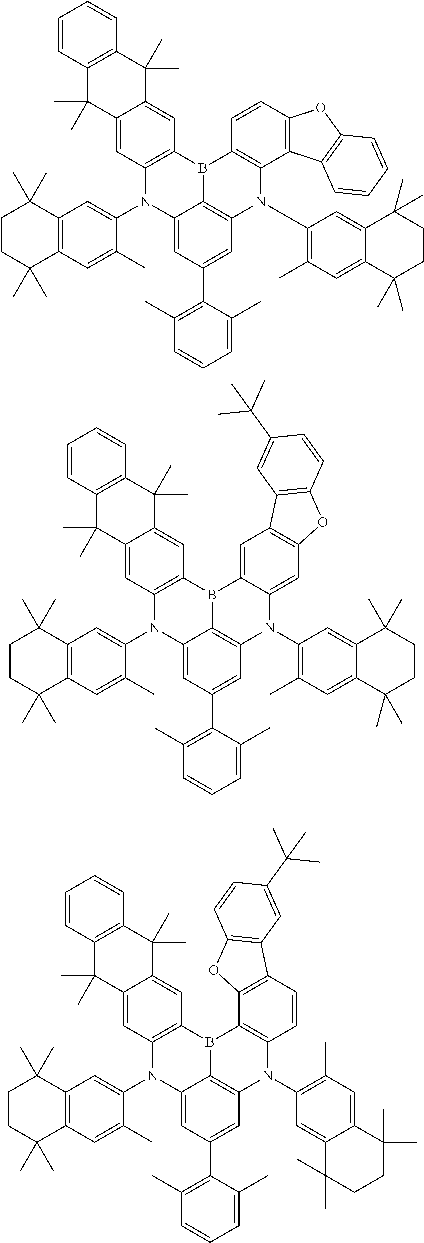

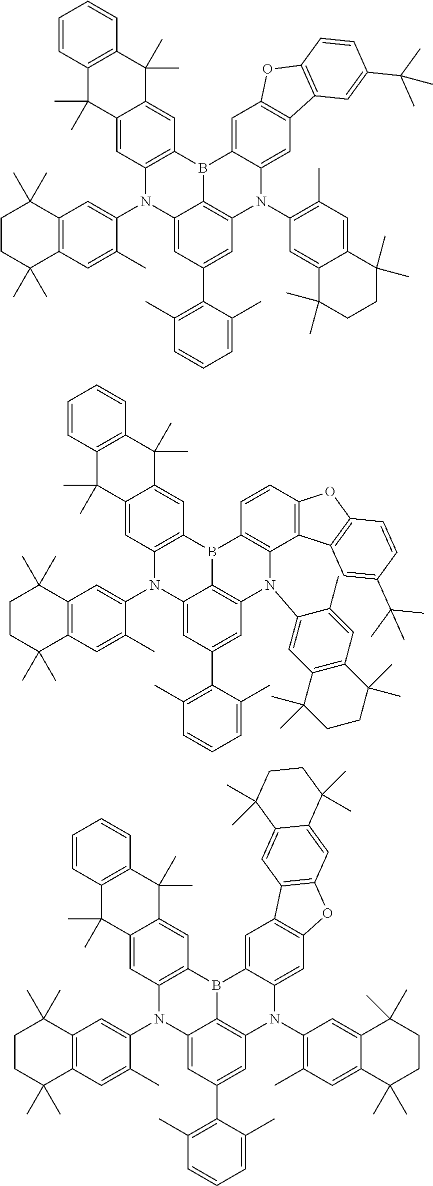

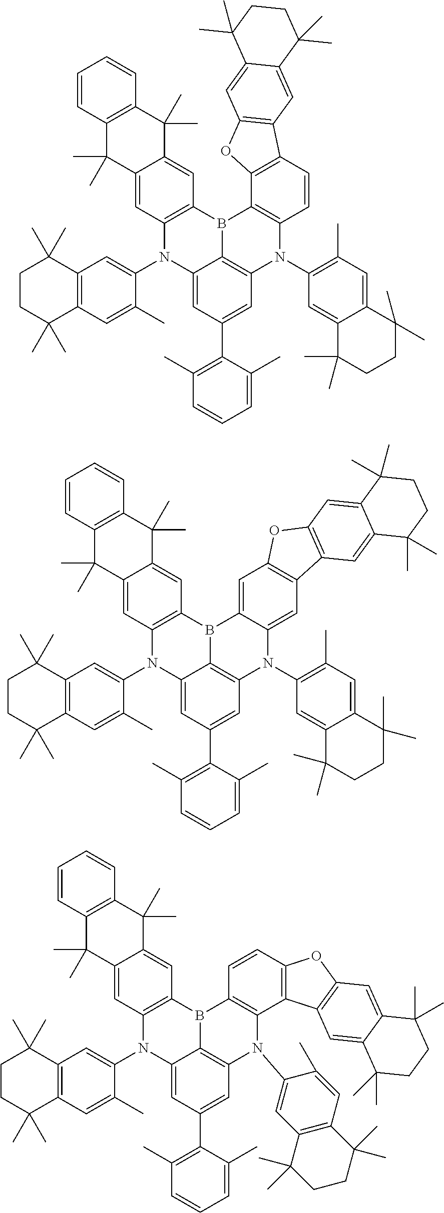 [SMILES: Cc1cc2c(cc1N1c3cc4c(cc3B3c5c1cc(-c1c(C)cccc1C)cc5N(c1cc5c(cc1C)C(C)(C)CCC5(C)C)c1ccc5c(oc6cc7c(cc65)C(C)(C)CCC7(C)C)c13)C(C)(C)c1ccccc1C4(C)C)C(C)(C)CCC2(C)C ; Cc1cc2c(cc1N1c3cc4c(cc3B3c5cc6oc7cc8c(cc7c6cc5N(c5cc6c(cc5C)C(C)(C)CCC6(C)C)c5cc(-c6c(C)cccc6C)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6oc7cc8c(cc7c6c5N(c5cc6c(cc5C)C(C)(C)CCC6(C)C)c5cc(-c6c(C)cccc6C)cc1c53)C(C)(C)CCC8(C)C)C(C)(C)c1ccccc1C4(C)C)C(C)(C)CCC2(C)C]

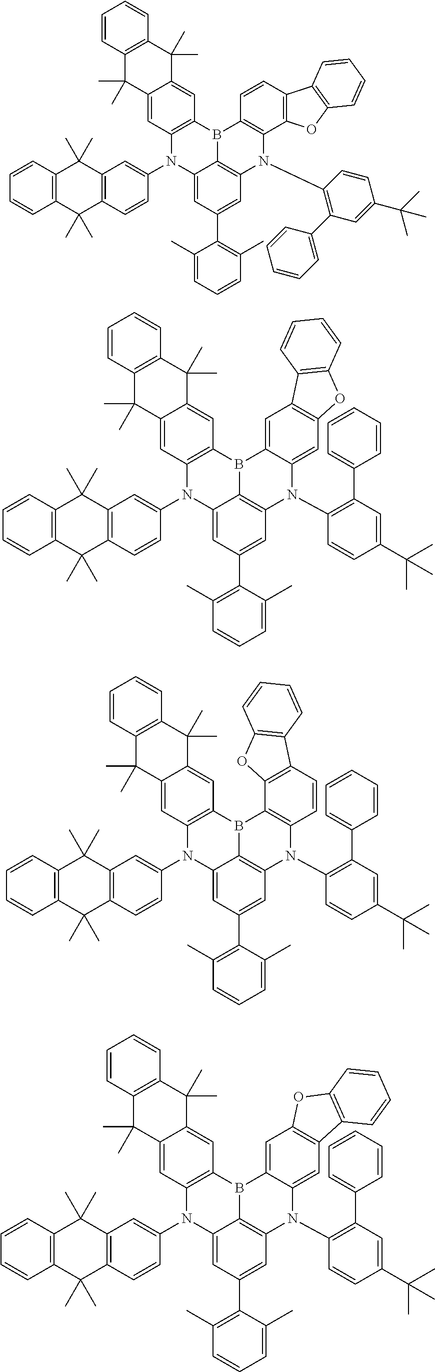

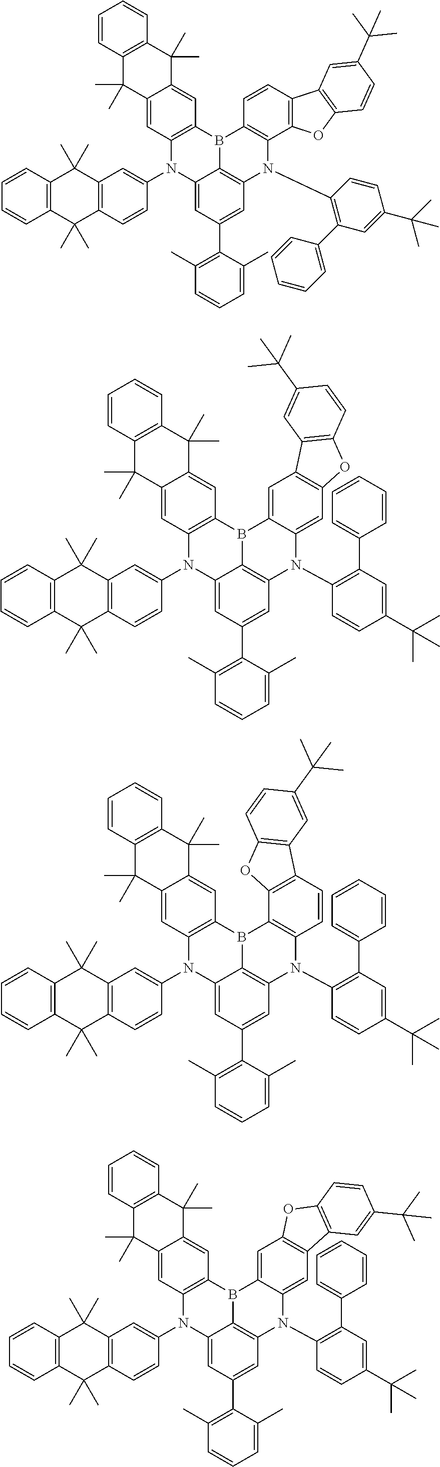

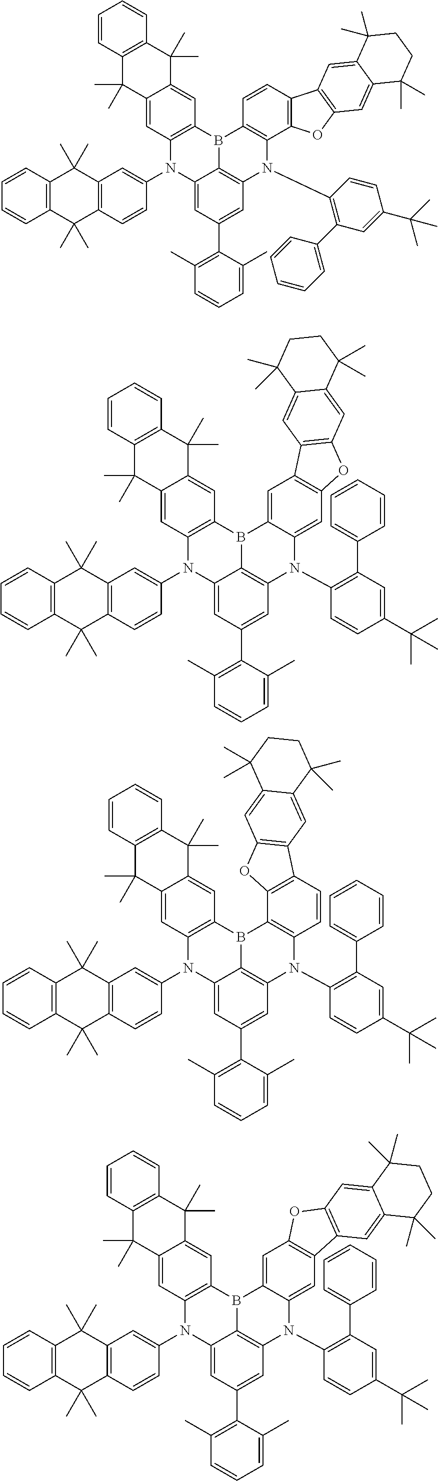

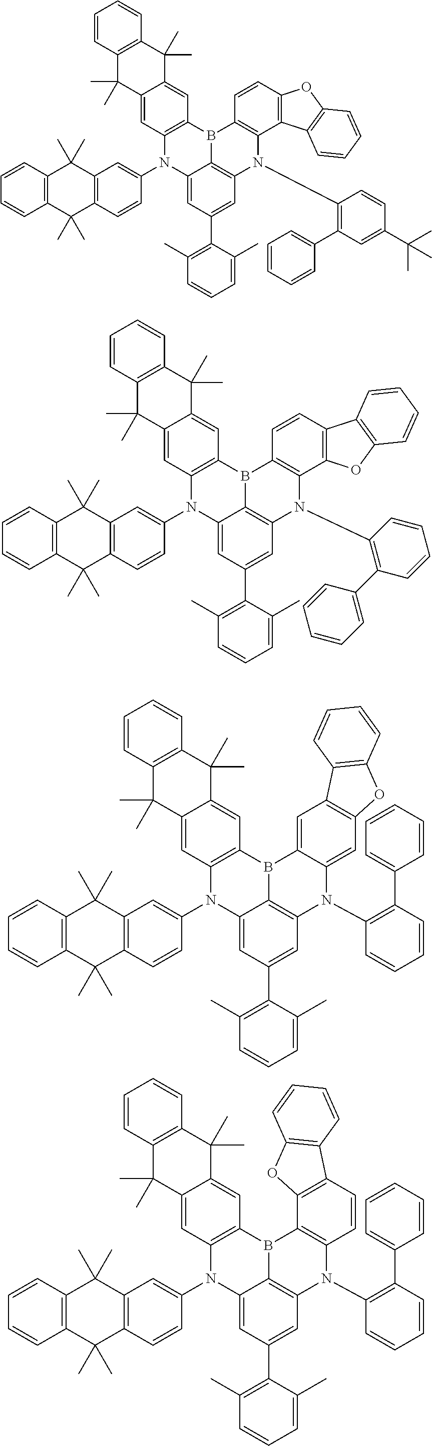

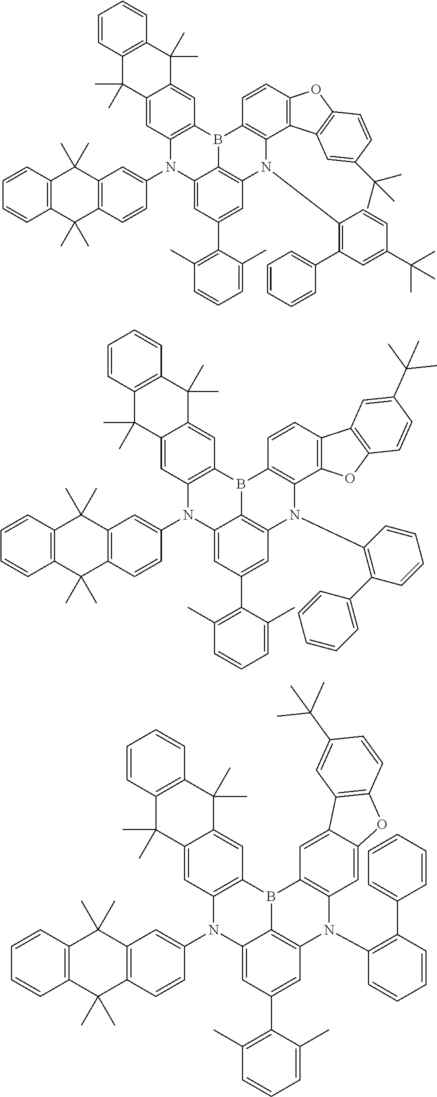

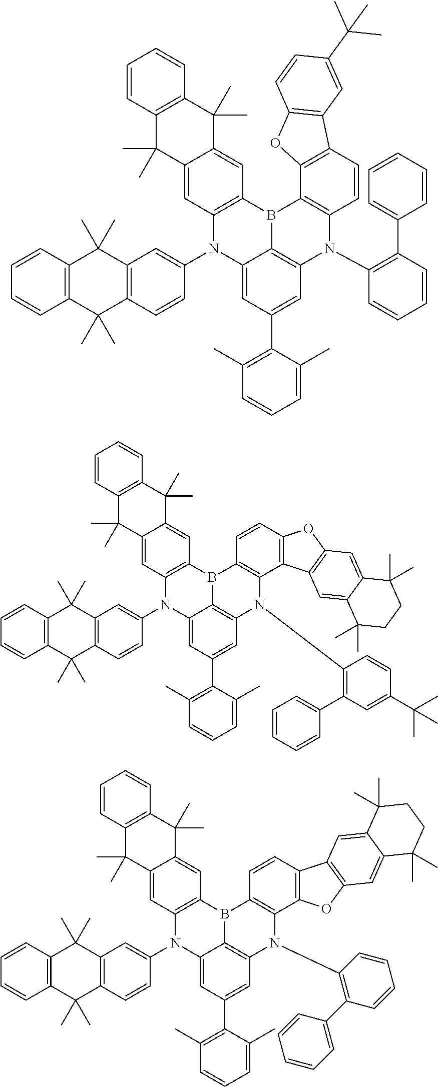 [SMILES: Cc1cccc(C)c1-c1cc2c3c(c1)N(c1ccccc1-c1ccccc1)c1ccc4c(oc5ccc(C(C)(C)C)cc54)c1B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1c(ccc4c1oc1cc5c(cc14)C(C)(C)CCC5(C)C)B3c1cc3c(cc1N2c1ccc2c(c1)C(C)(C)c1ccccc1C2(C)C)C(C)(C)c1ccccc1C3(C)C]

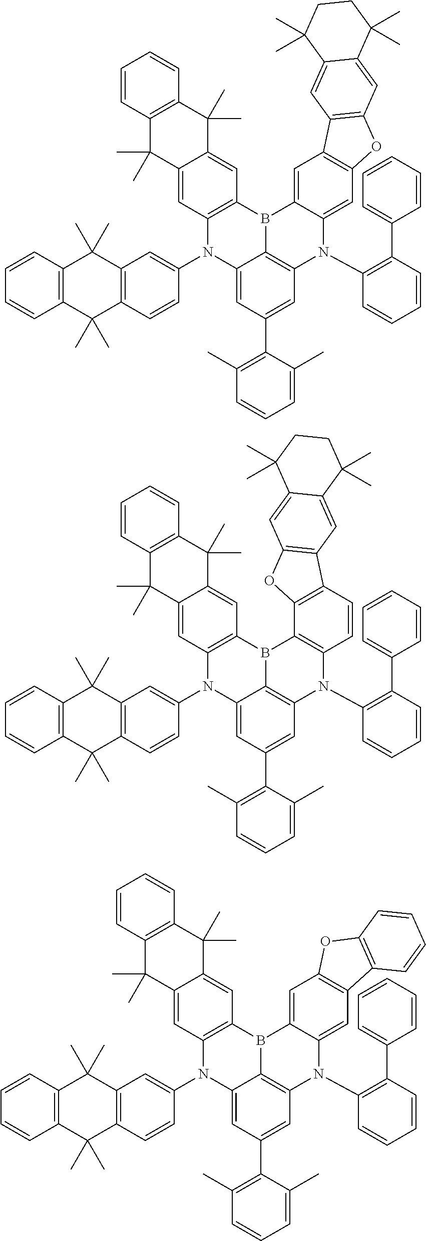

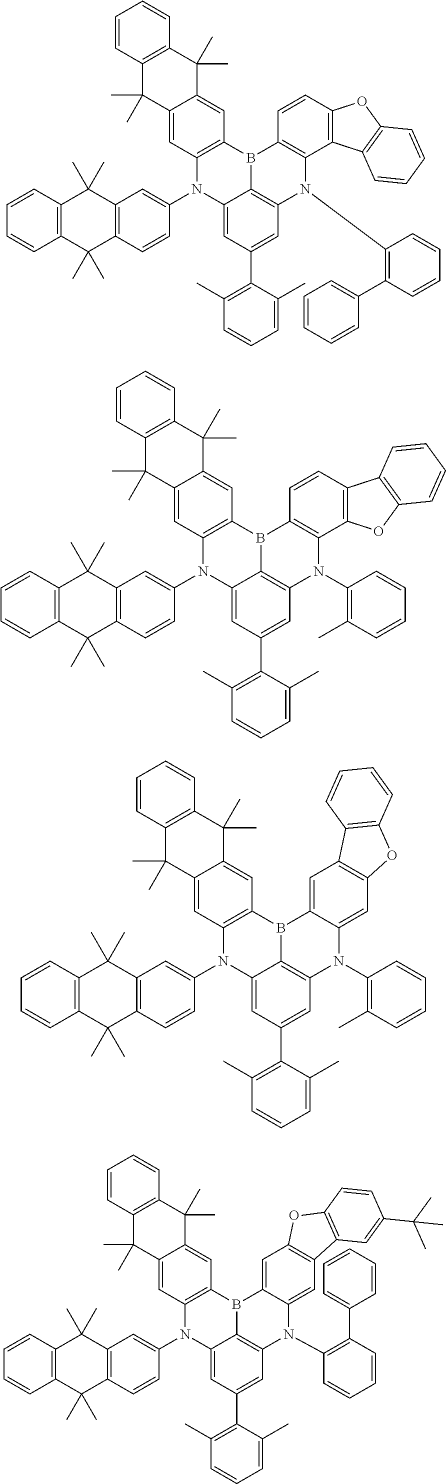

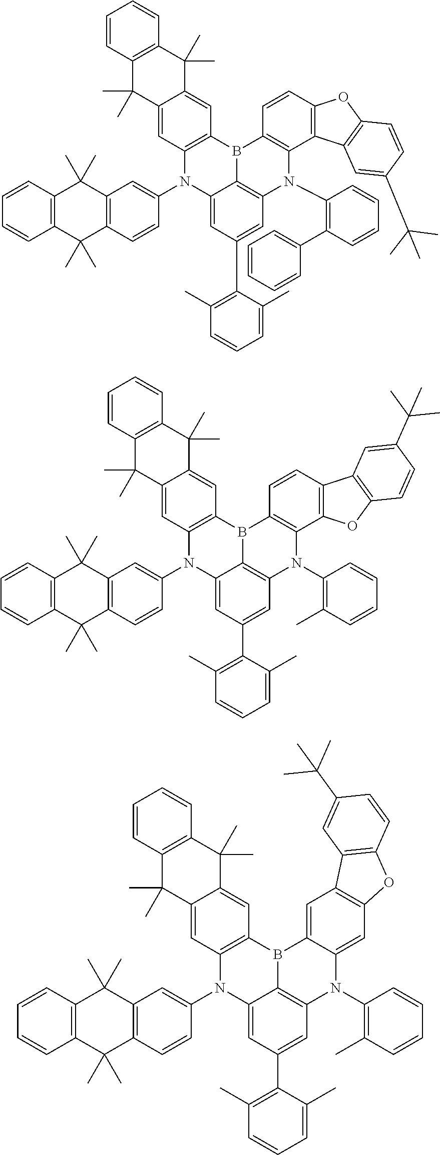 [SMILES: Cc1cccc(C)c1-c1cc2c3c(c1)N(c1ccccc1-c1ccccc1)c1c(ccc4oc5ccc(C(C)(C)C)cc5c14)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)c3ccccc3C5(C)C)c3cc(-c5c(C)cccc5C)cc1c32)C(C)(C)c1ccccc1C4(C)C]

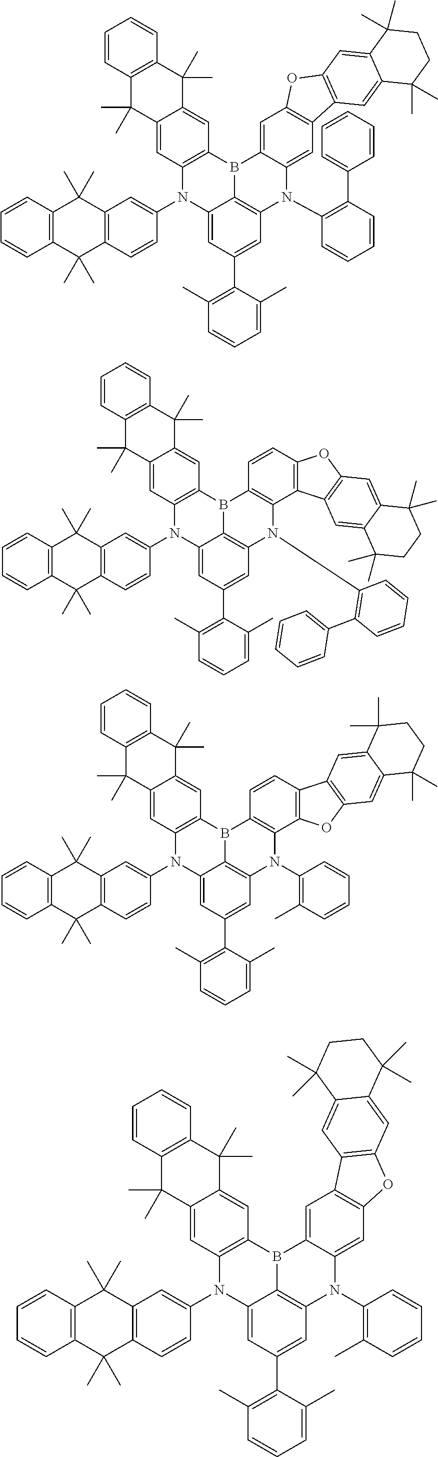

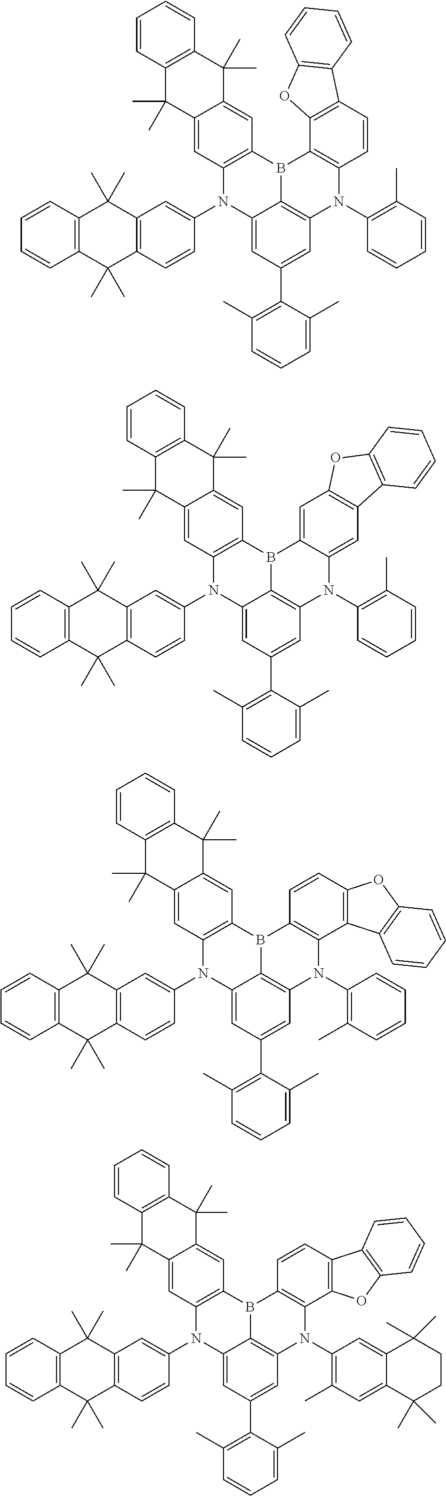

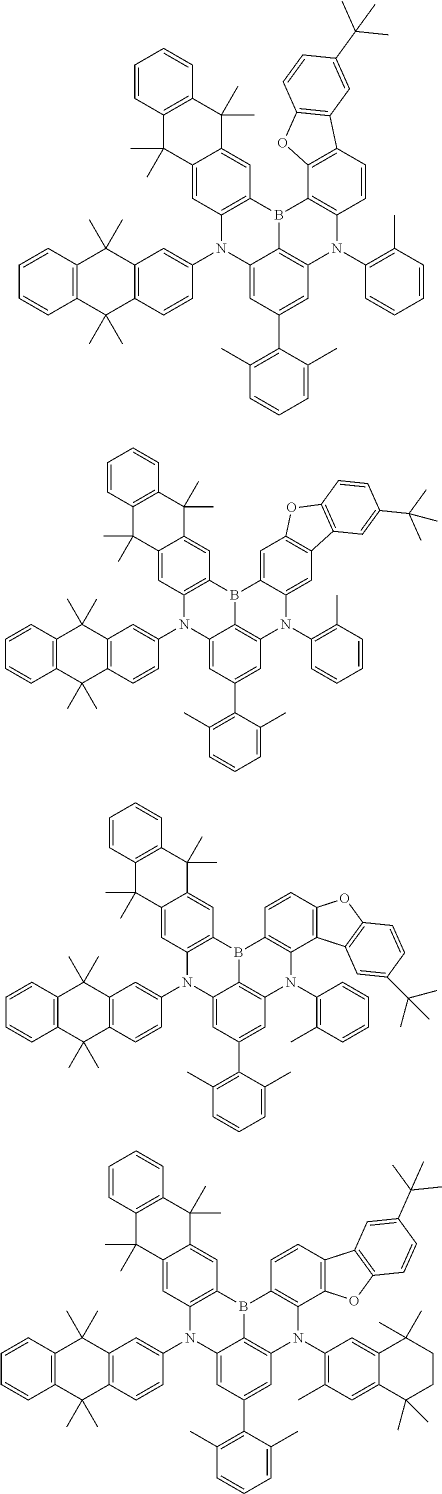

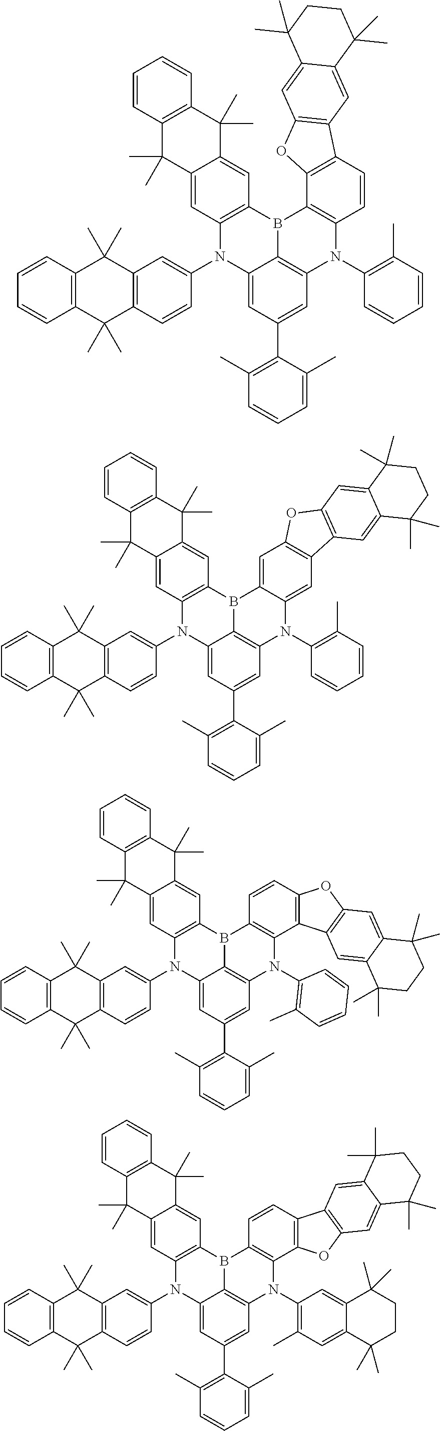

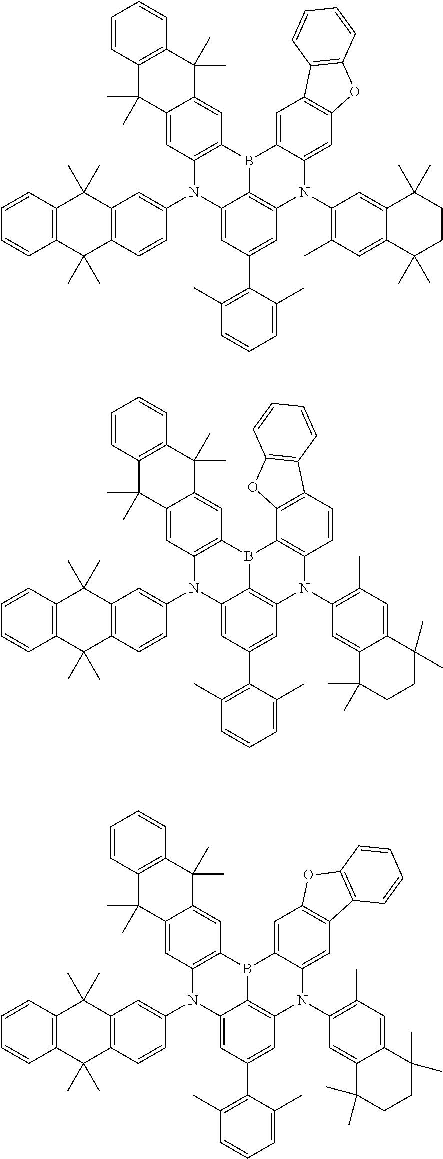 [SMILES: Cc1cc2c(cc1N1c3cc4oc5ccccc5c4cc3B3c4cc5c(cc4N(c4ccc6c(c4)C(C)(C)c4ccccc4C6(C)C)c4cc(-c6c(C)cccc6C)cc1c43)C(C)(C)c1ccccc1C5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3oc3ccccc31)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)oc1ccccc14)C(C)(C)CCC2(C)C]

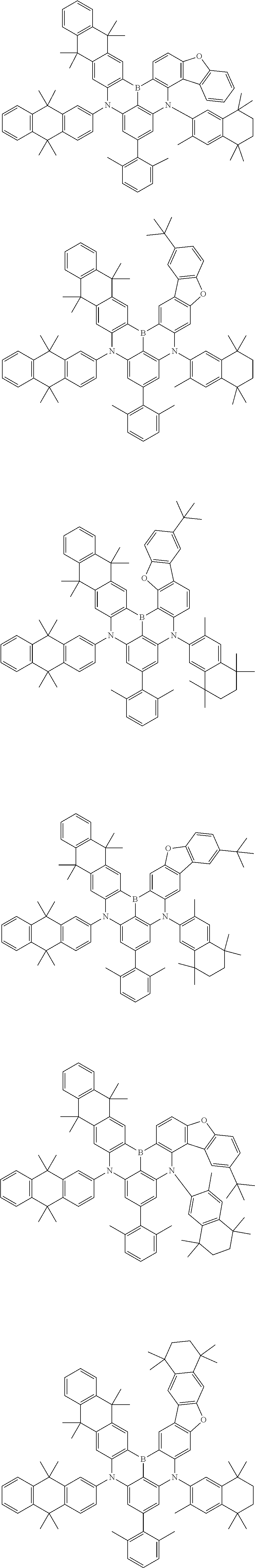

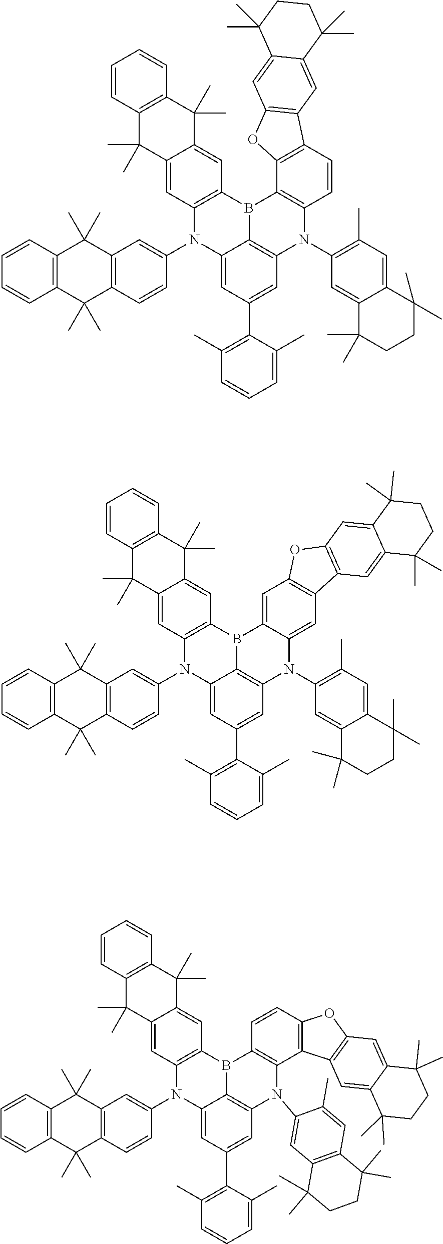 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3oc3cc4c(cc31)C(C)(C)CCC4(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)oc1cc3c(cc14)C(C)(C)CCC3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4oc5cc6c(cc5c4c31)C(C)(C)CCC6(C)C)C(C)(C)CCC2(C)C]

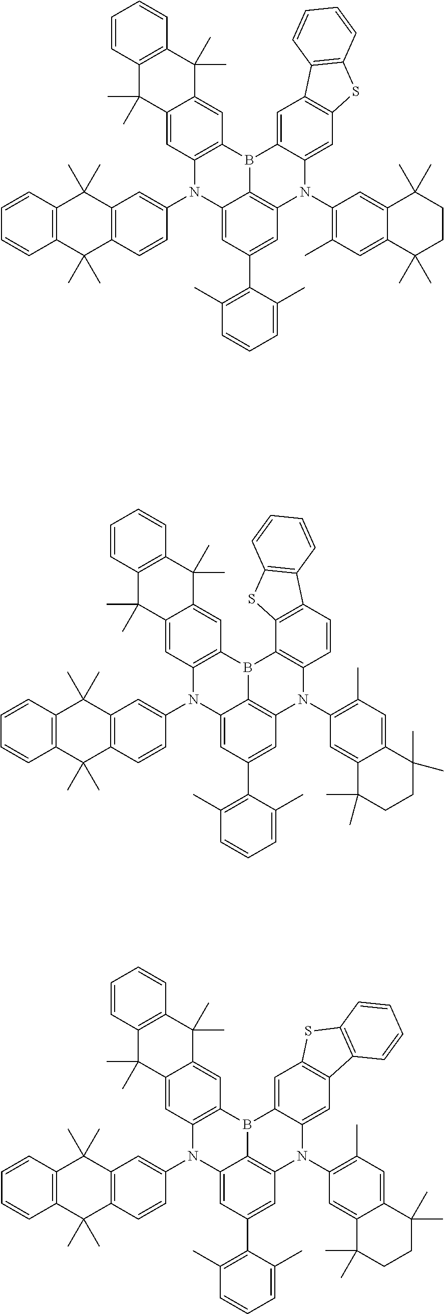 [SMILES: Cc1cc2c(cc1N1c3cc4sc5ccccc5c4cc3B3c4cc5c(cc4N(c4ccc6c(c4)C(C)(C)c4ccccc4C6(C)C)c4cc(-c6c(C)cccc6C)cc1c43)C(C)(C)c1ccccc1C5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3sc3ccccc31)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)sc1ccccc14)C(C)(C)CCC2(C)C]

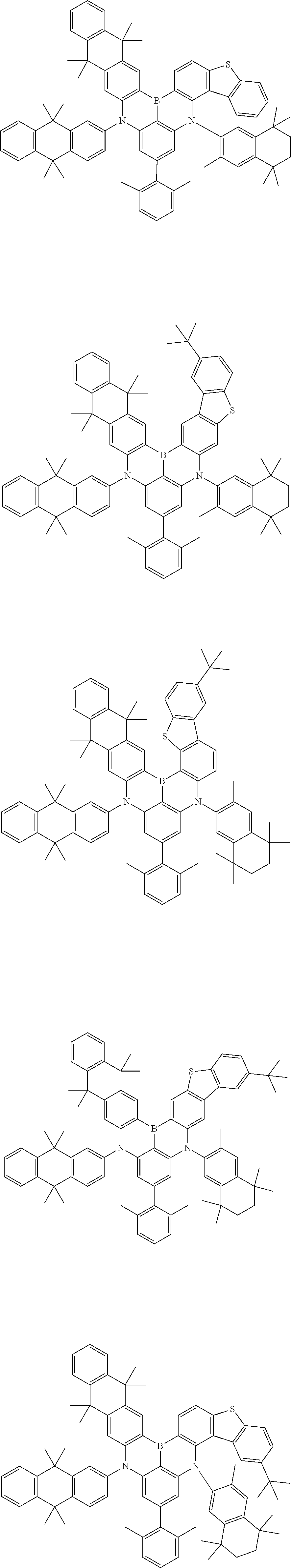

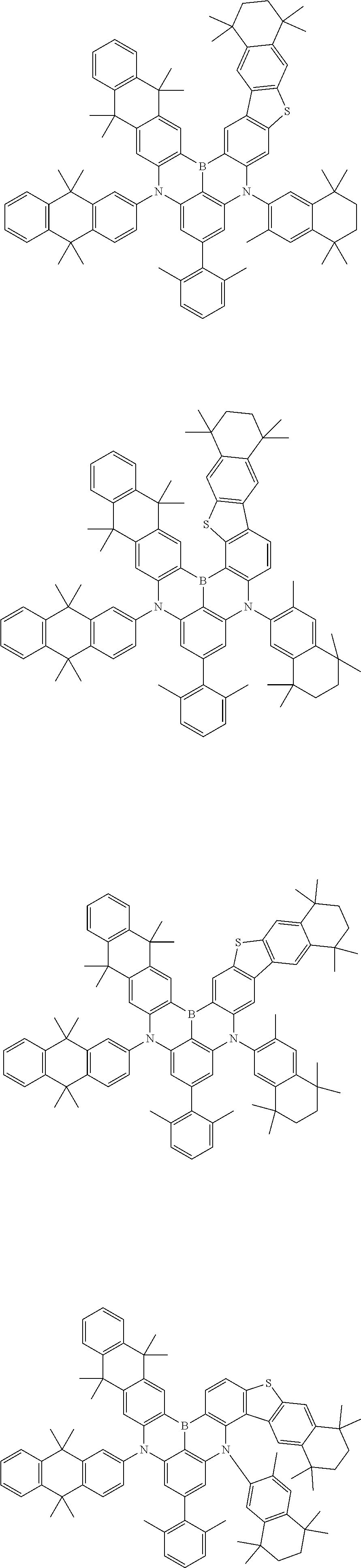

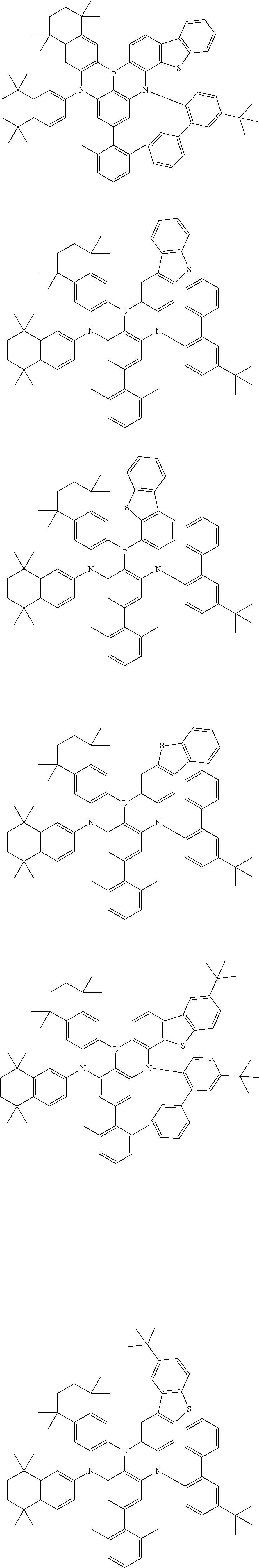

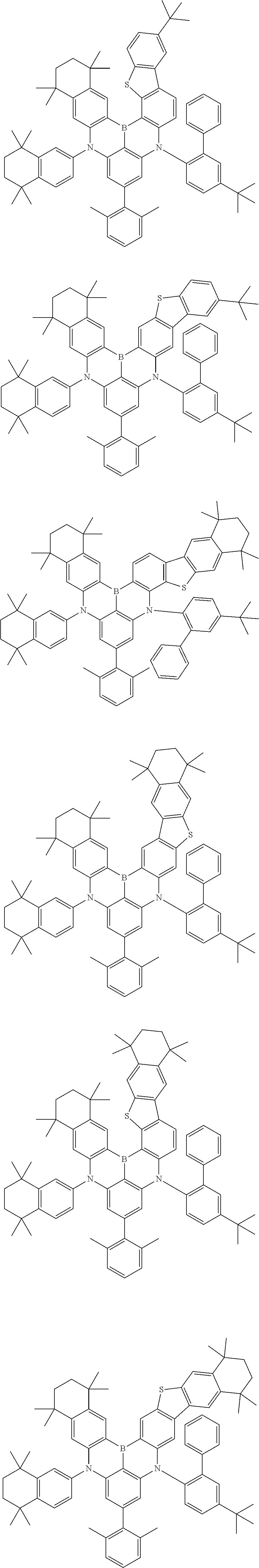

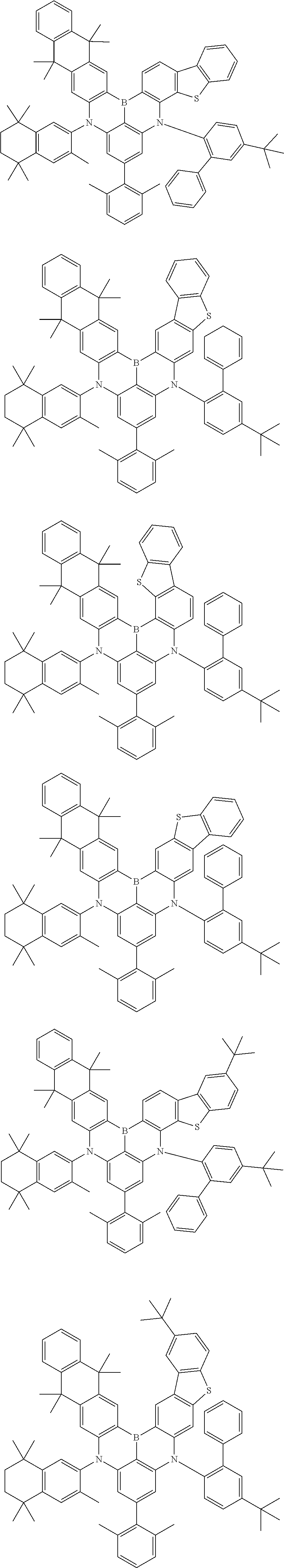

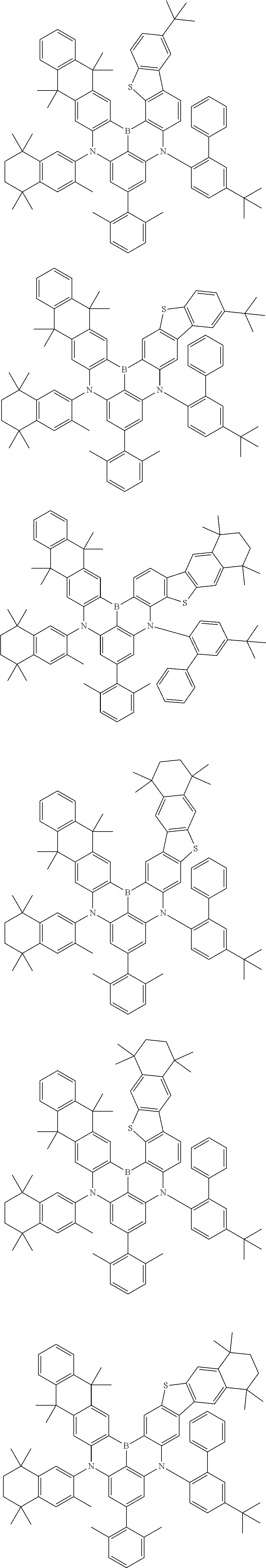

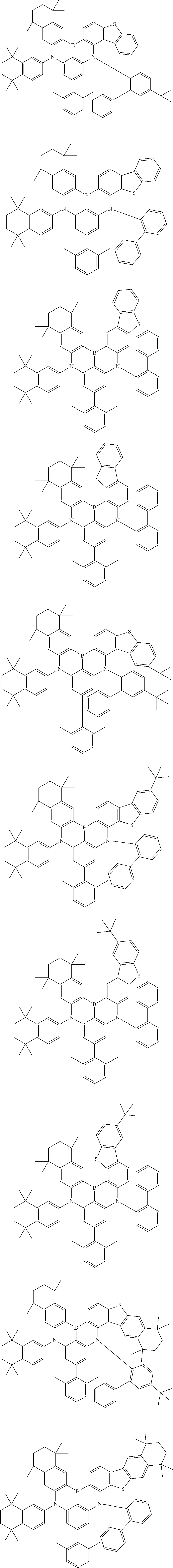

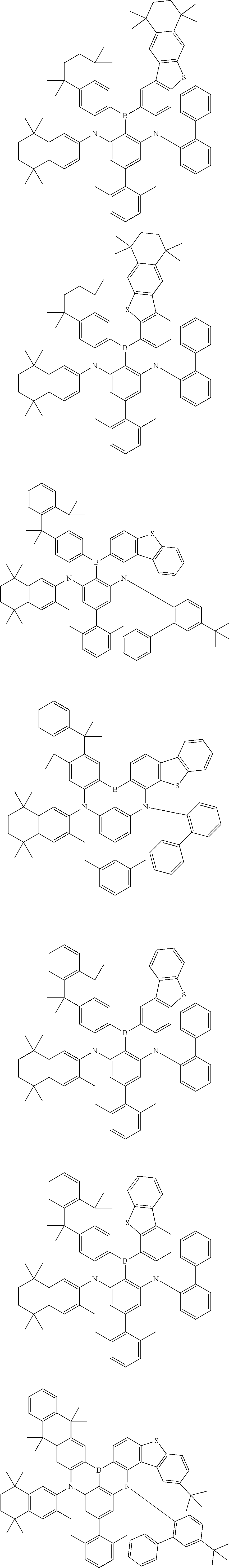

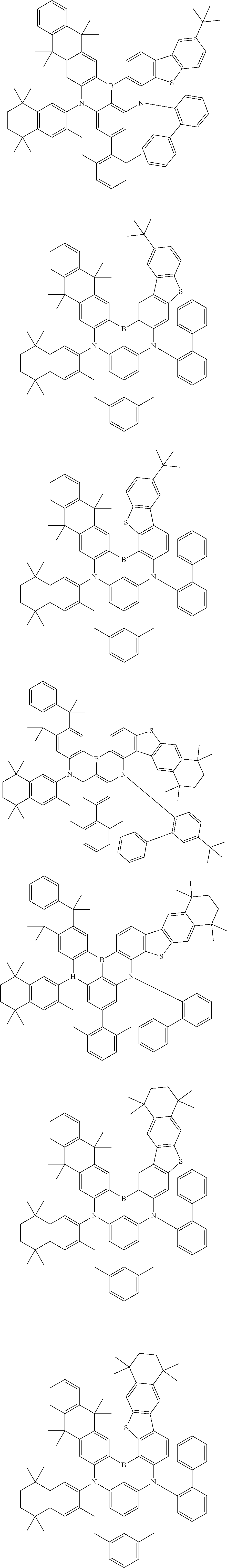

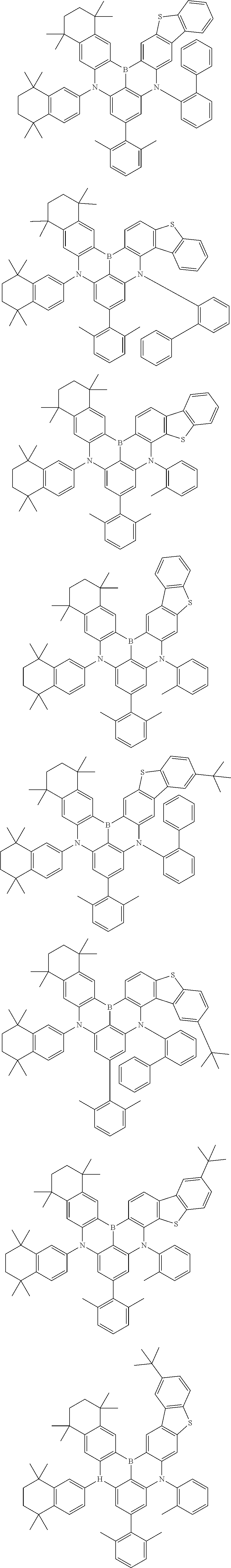

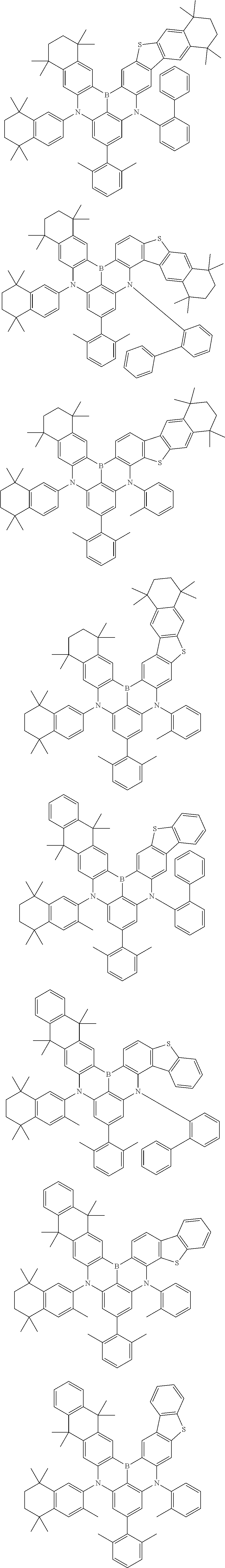

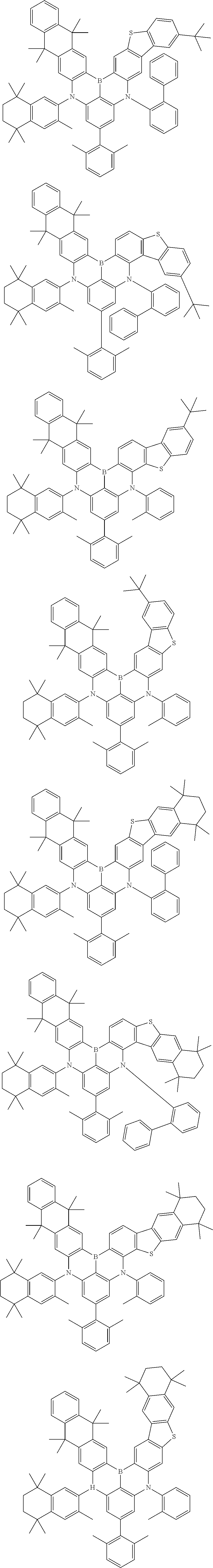

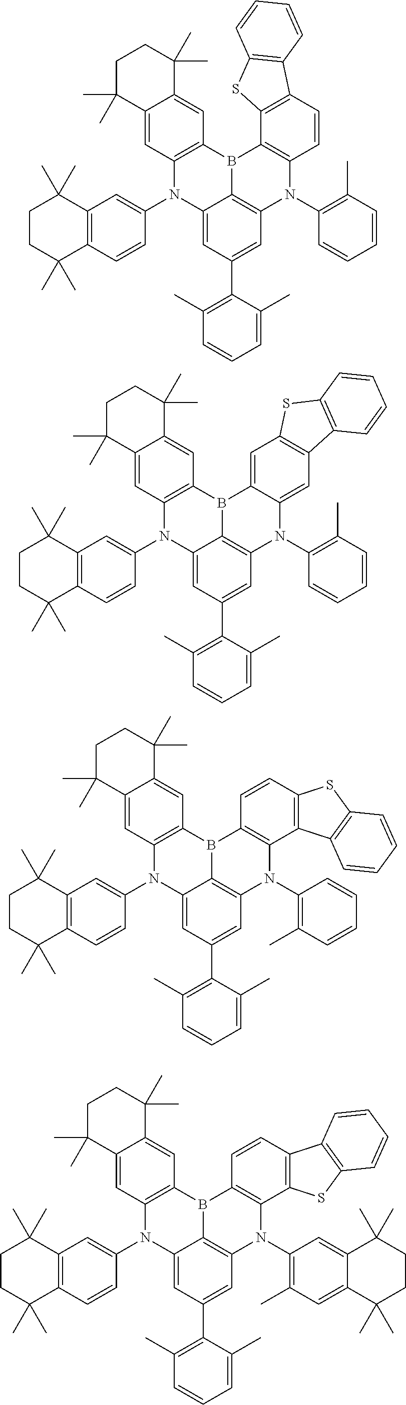

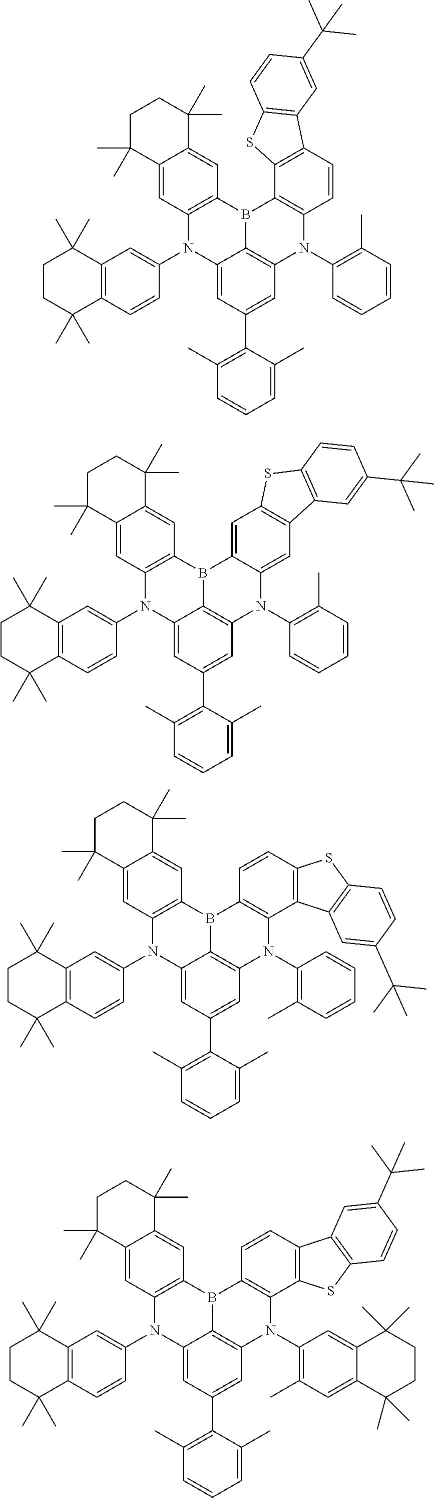

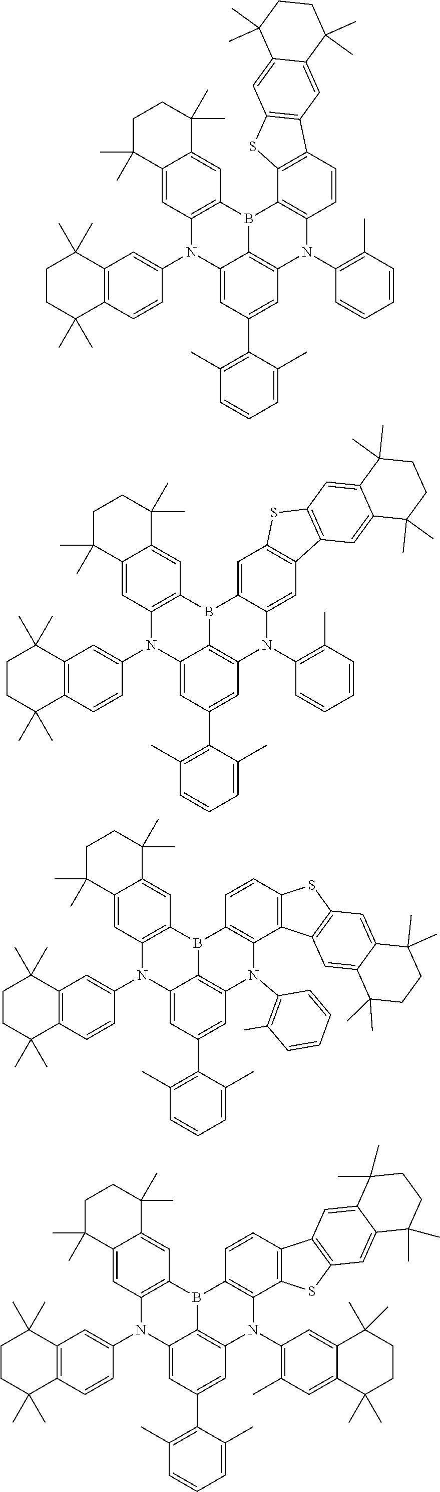

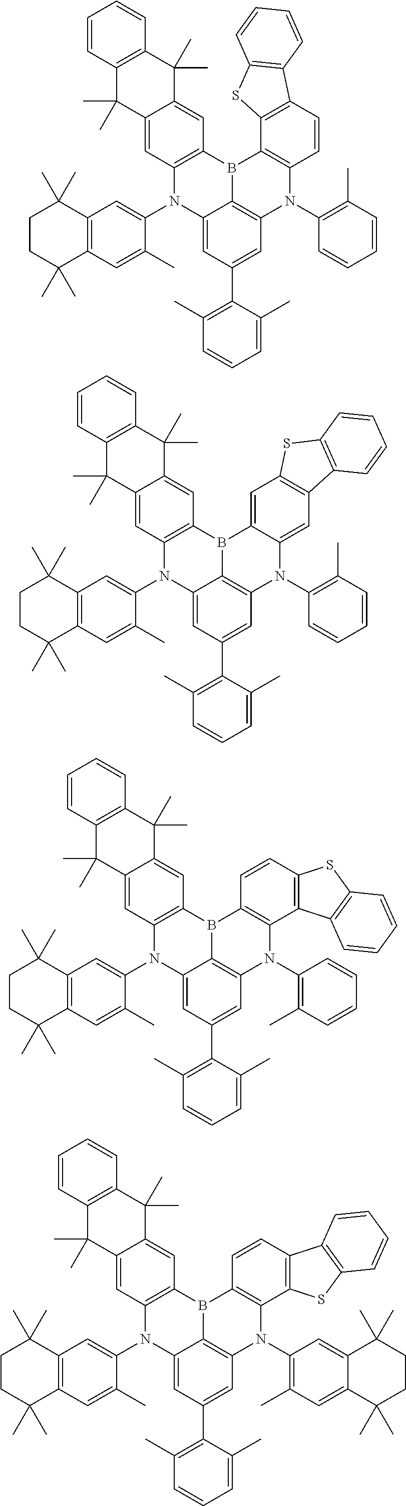

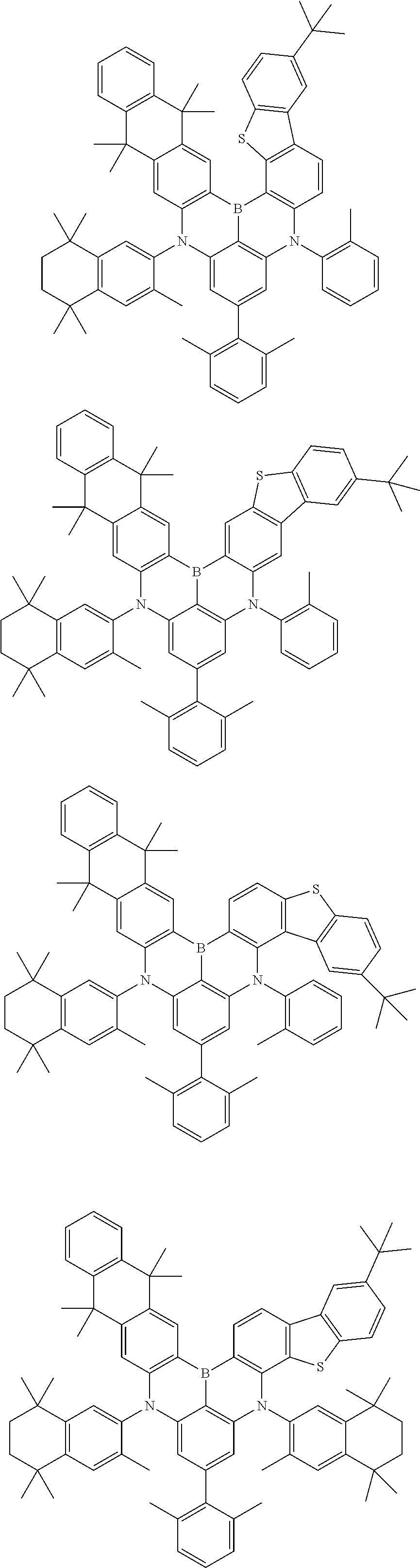

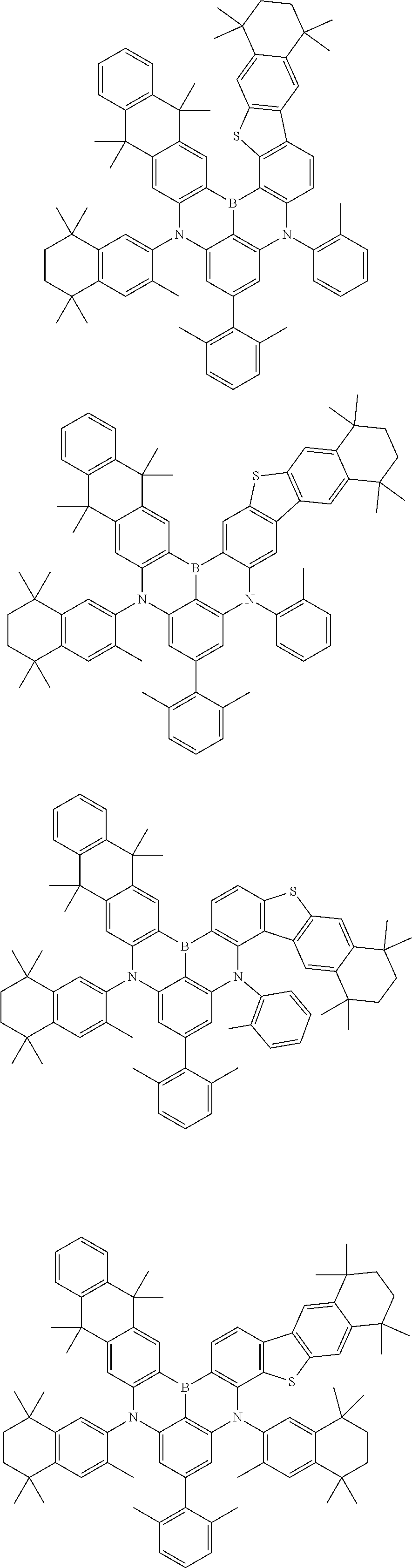

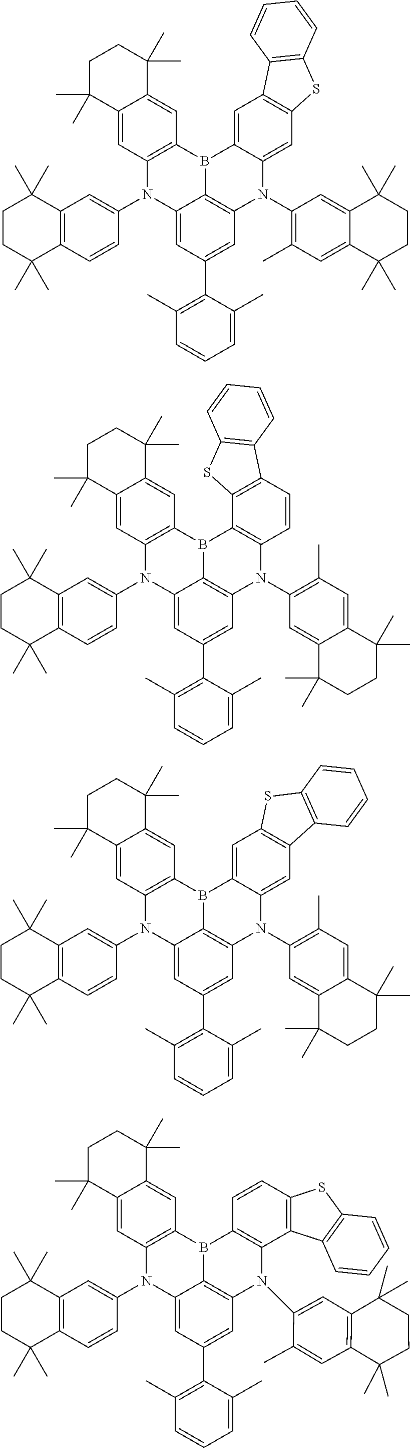

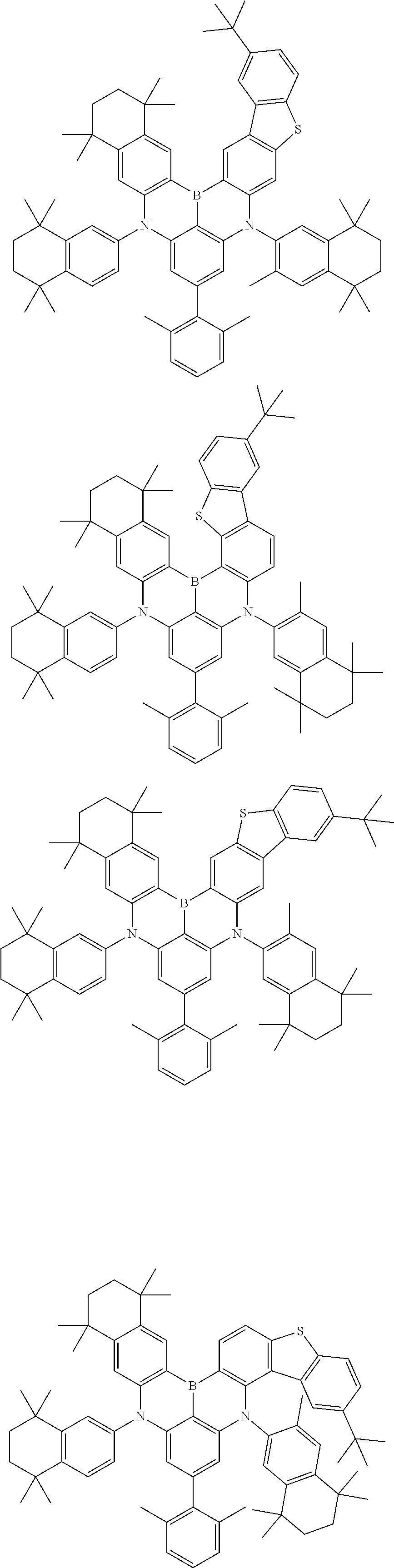

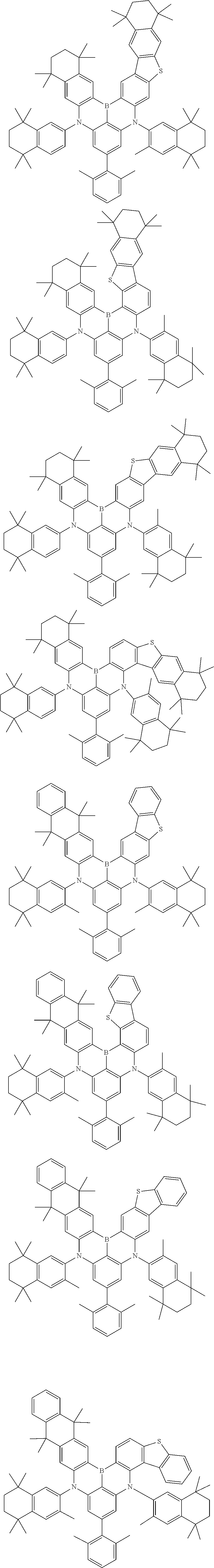

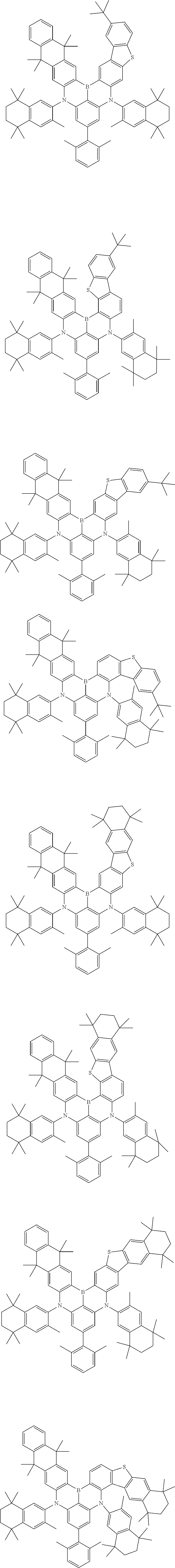

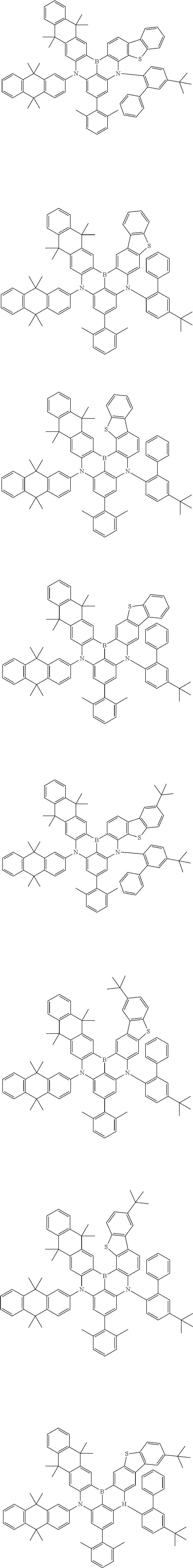

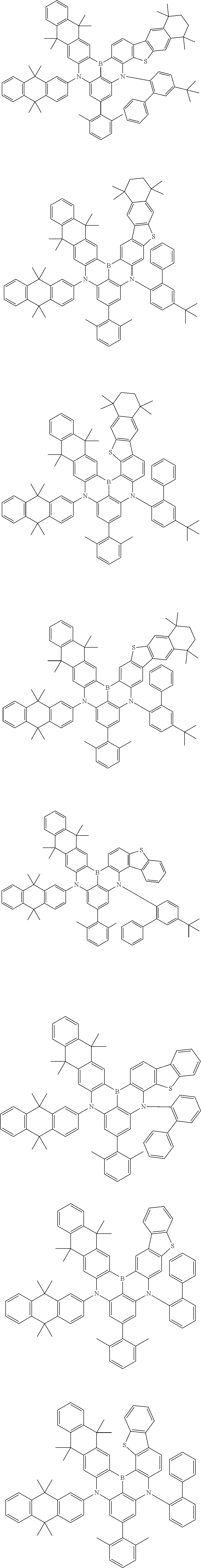

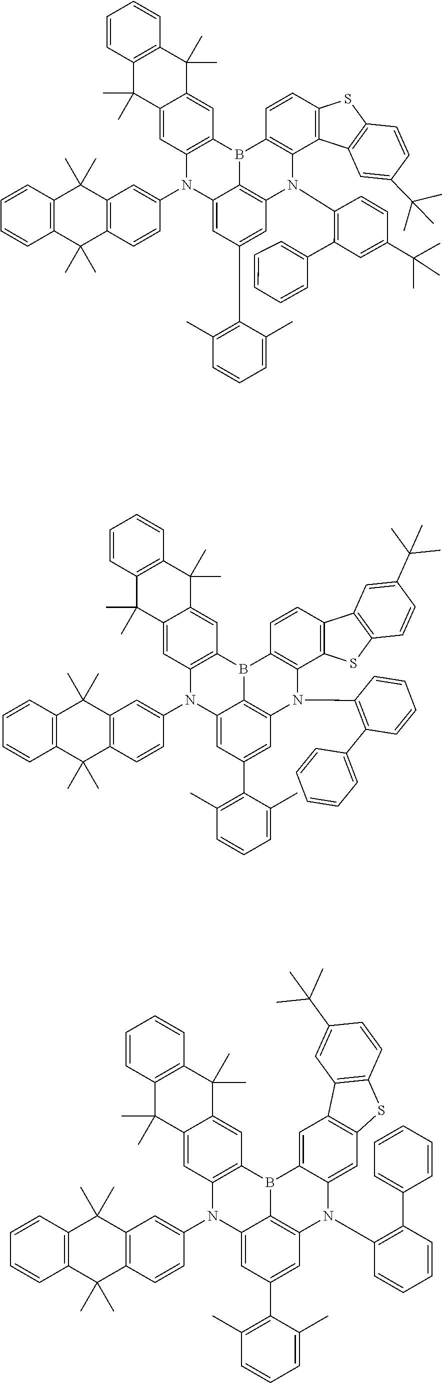 [SMILES: Cc1cccc(C)c1-c1cc2c3c(c1)N(c1ccc(C(C)(C)C)cc1-c1ccccc1)c1c(ccc4sc5ccc(C(C)(C)C)cc5c14)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1c(ccc4c1sc1ccc(C(C)(C)C)cc14)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1cc4sc5ccc(C(C)(C)C)cc5c4cc1B3c1cc3c(cc1N2c1ccc2c(c1)C(C)(C)c1ccccc1C2(C)C)C(C)(C)c1ccccc1C3(C)C]

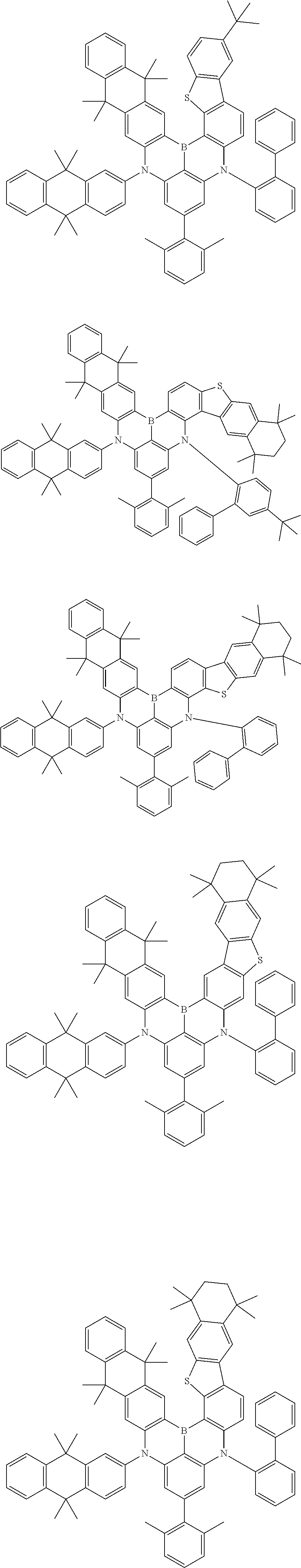

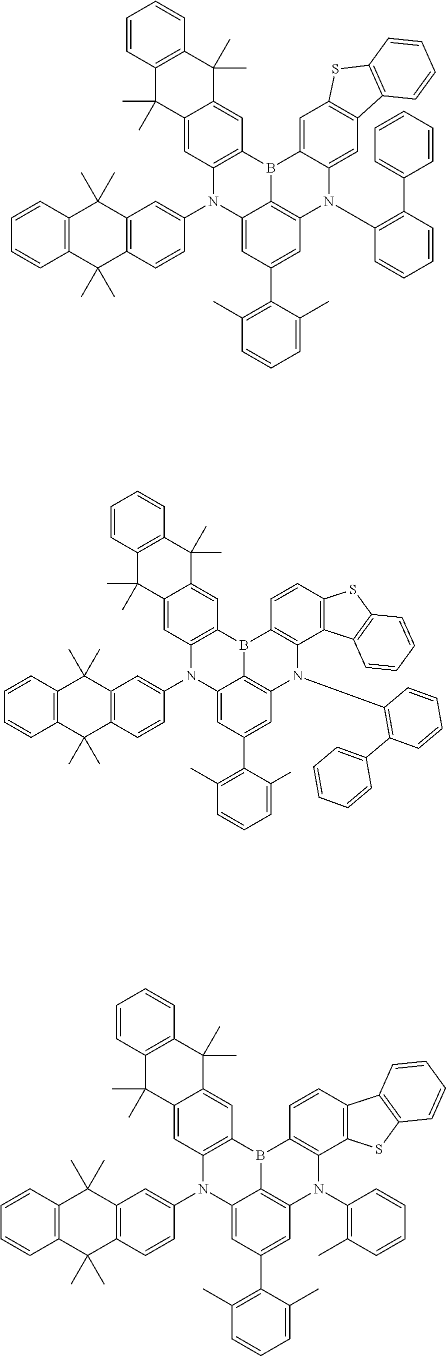 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1ccccc14 ; Cc1cccc(C)c1-c1cc2c3c(c1)N(c1ccccc1-c1ccccc1)c1c(ccc4sc5ccccc5c14)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(sc4ccccc43)c21]

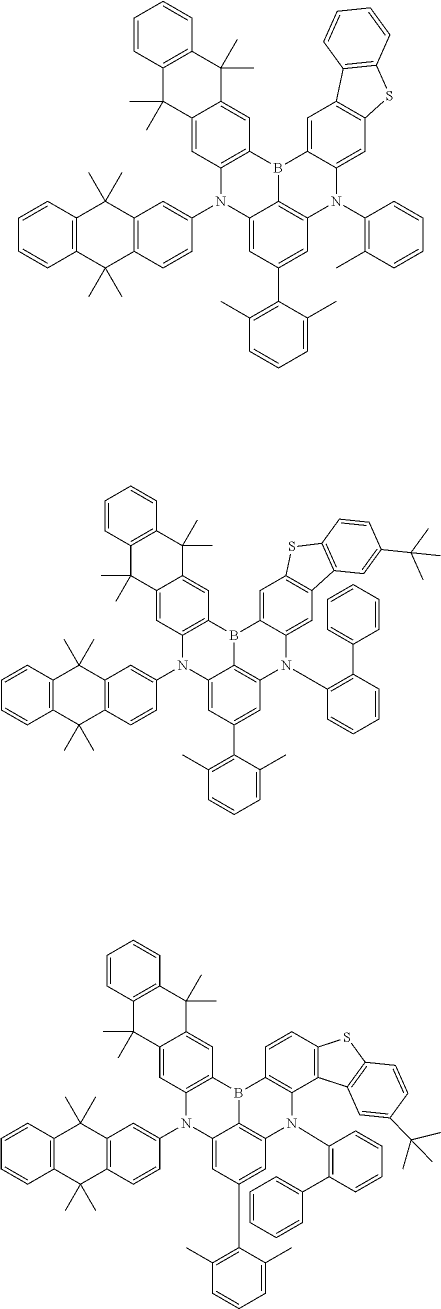 [SMILES: Cc1ccccc1N1c2cc3sc4ccccc4c3cc2B2c3cc4c(cc3N(c3ccc5c(c3)C(C)(C)c3ccccc3C5(C)C)c3cc(-c5c(C)cccc5C)cc1c32)C(C)(C)c1ccccc1C4(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1ccc(C(C)(C)C)cc14 ; Cc1cccc(C)c1-c1cc2c3c(c1)N(c1ccccc1-c1ccccc1)c1c(ccc4sc5ccc(C(C)(C)C)cc5c14)B3c1cc3c(cc1N2c1ccc2c(c1)C(C)(C)c1ccccc1C2(C)C)C(C)(C)c1ccccc1C3(C)C]

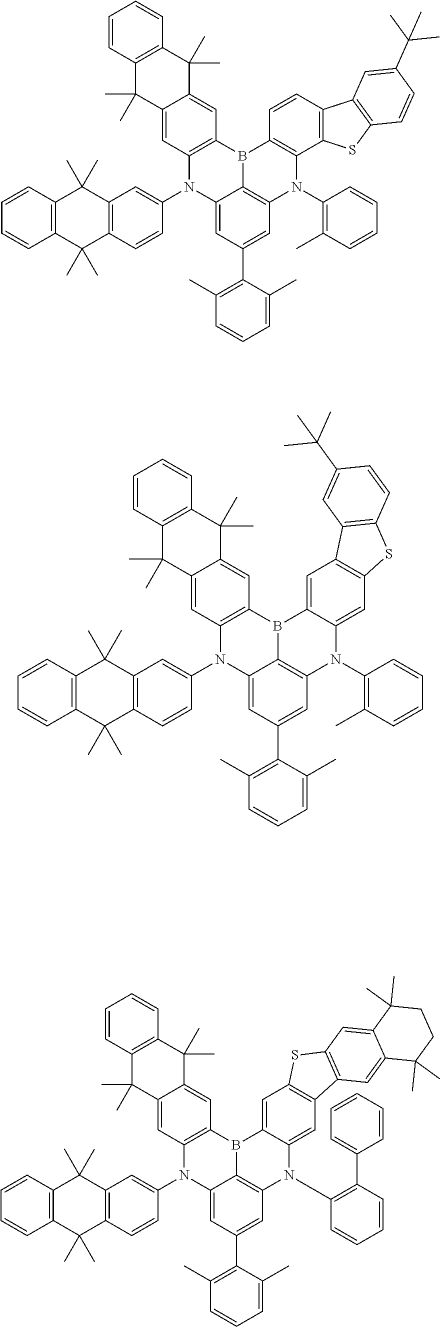 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(sc4ccc(C(C)(C)C)cc43)c21 ; Cc1ccccc1N1c2cc3sc4ccc(C(C)(C)C)cc4c3cc2B2c3cc4c(cc3N(c3ccc5c(c3)C(C)(C)c3ccccc3C5(C)C)c3cc(-c5c(C)cccc5C)cc1c32)C(C)(C)c1ccccc1C4(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)sc1cc2c(cc14)C(C)(C)CCC2(C)C]

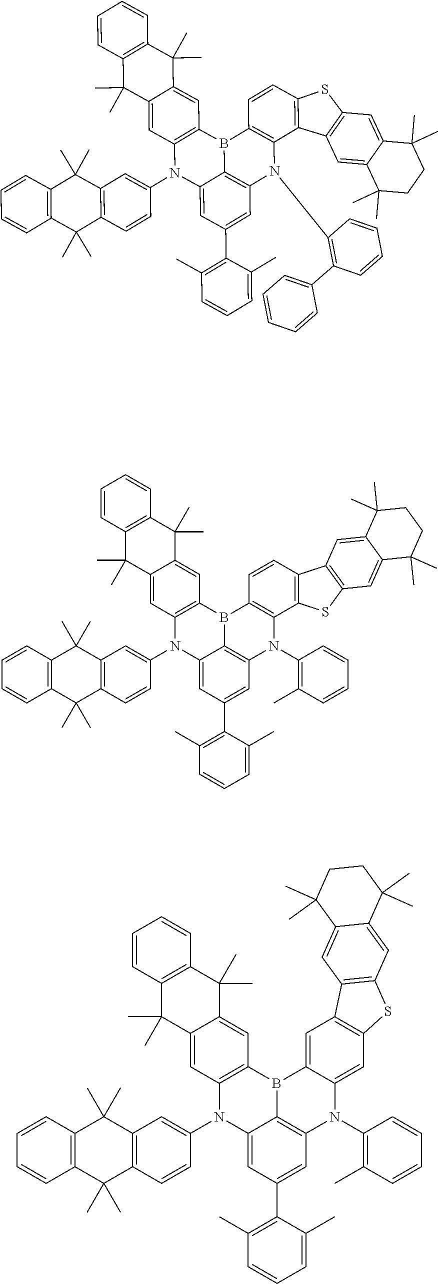 [SMILES: Cc1cccc(C)c1-c1cc2c3c(c1)N(c1ccccc1-c1ccccc1)c1c(ccc4sc5cc6c(cc5c14)C(C)(C)CCC6(C)C)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(sc4cc5c(cc43)C(C)(C)CCC5(C)C)c21 ; Cc1ccccc1N1c2cc3sc4cc5c(cc4c3cc2B2c3cc4c(cc3N(c3ccc6c(c3)C(C)(C)c3ccccc3C6(C)C)c3cc(-c6c(C)cccc6C)cc1c32)C(C)(C)c1ccccc1C4(C)C)C(C)(C)CCC5(C)C]

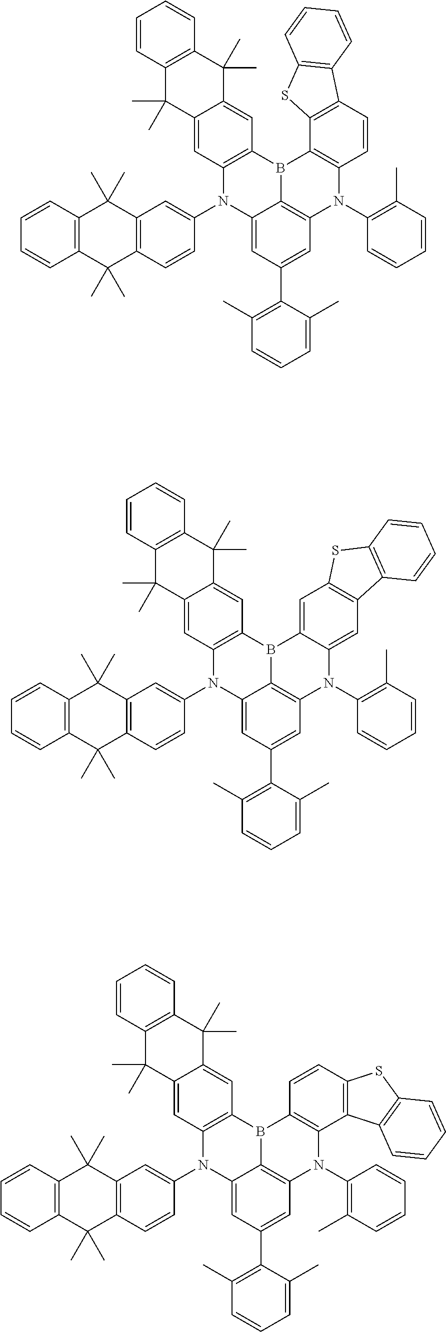 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2sc2ccccc21 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)sc1ccccc13 ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3sc4ccccc4c3c21]

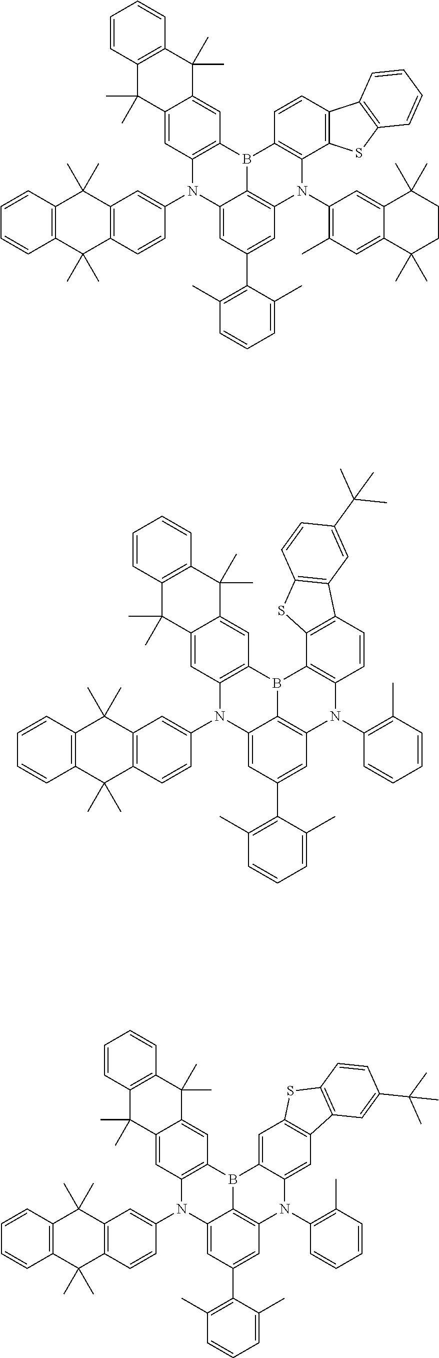 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(sc5ccccc54)c31)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2sc2ccc(C(C)(C)C)cc21 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)sc1ccc(C(C)(C)C)cc13]

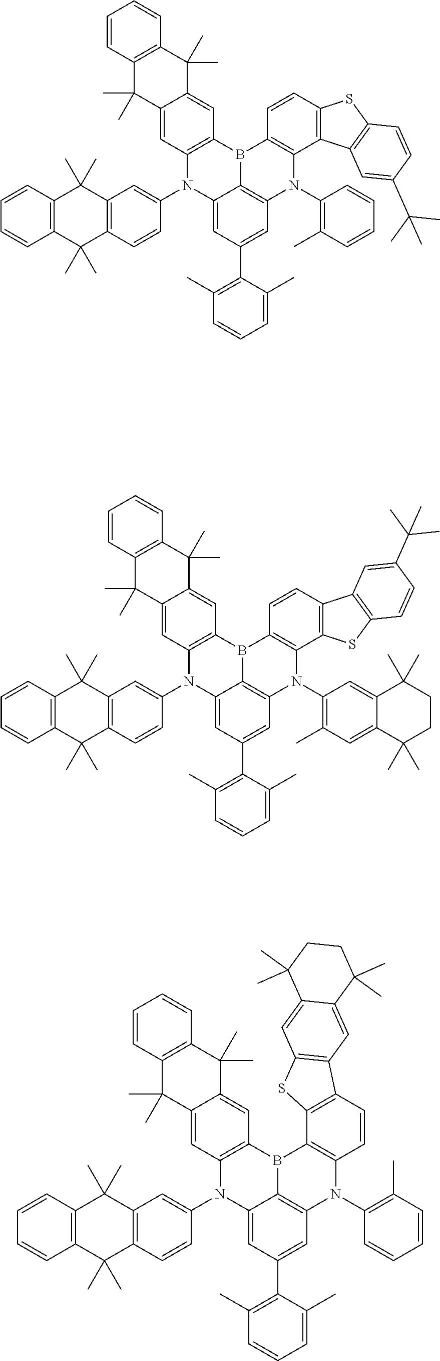 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3sc4ccc(C(C)(C)C)cc4c3c21 ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(sc5ccc(C(C)(C)C)cc54)c31)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2sc2cc3c(cc21)C(C)(C)CCC3(C)C]

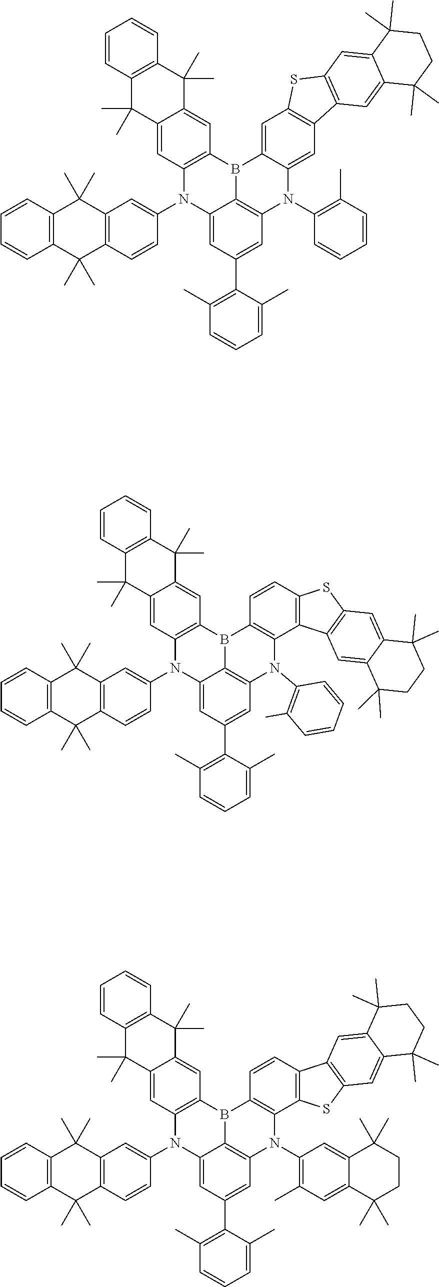 [SMILES: Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)sc1cc2c(cc13)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3sc4cc5c(cc4c3c21)C(C)(C)CCC5(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(sc5cc6c(cc54)C(C)(C)CCC6(C)C)c31)C(C)(C)CCC2(C)C]

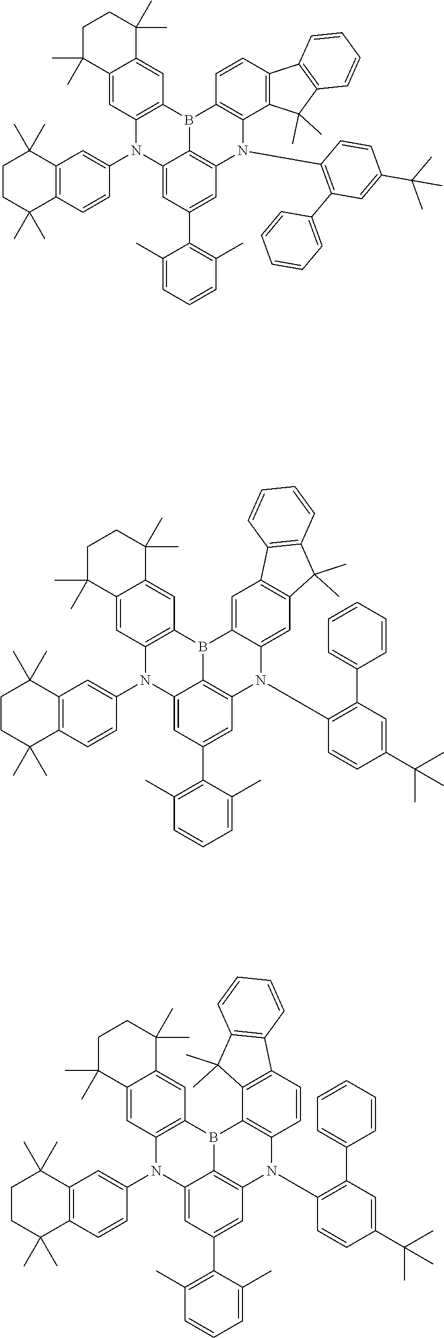 [SMILES: Cc1cccc(C)c1-c1cc2c3c(c1)N(c1ccc(C(C)(C)C)cc1-c1ccccc1)c1c(ccc4c1C(C)(C)c1ccccc1-4)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)-c1ccccc1C4(C)C ; Cc1cccc(C)c1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1ccccc1-4]

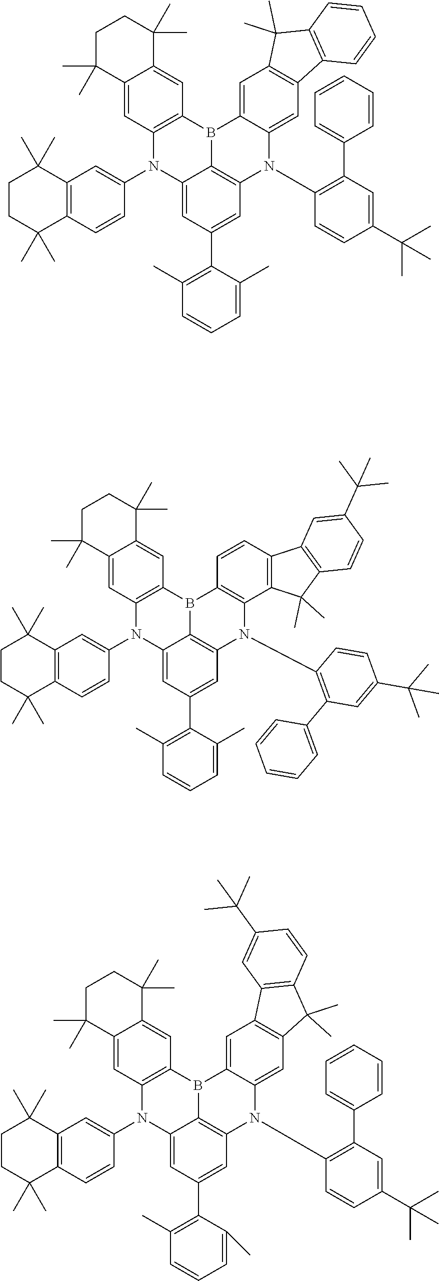 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1ccccc1-4 ; Cc1cccc(C)c1-c1cc2c3c(c1)N(c1ccc(C(C)(C)C)cc1-c1ccccc1)c1c(ccc4c1C(C)(C)c1ccc(C(C)(C)C)cc1-4)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)-c1cc(C(C)(C)C)ccc1C4(C)C]

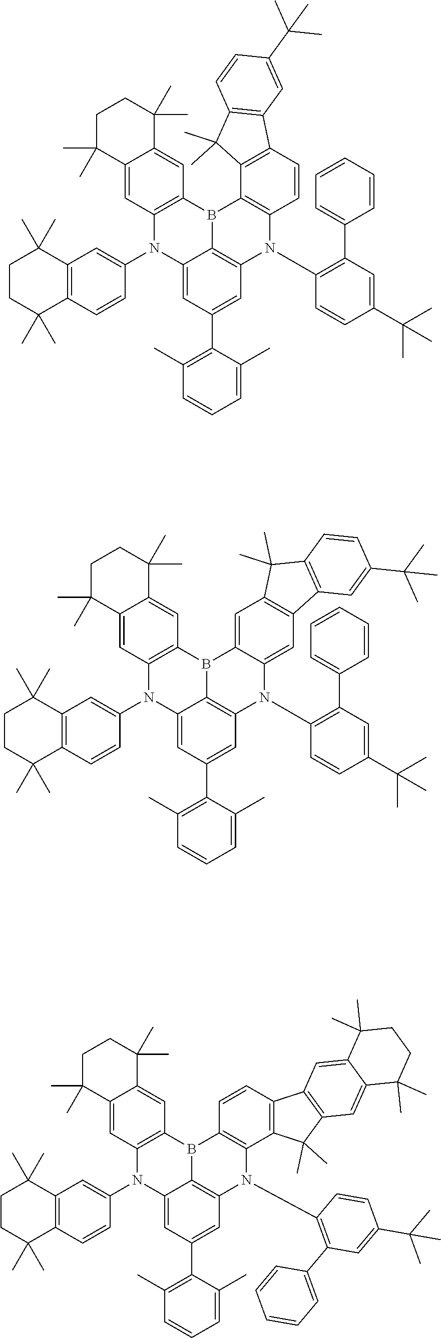 [SMILES: Cc1cccc(C)c1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1ccc(C(C)(C)C)cc1-4 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1ccc(C(C)(C)C)cc1-4 ; Cc1cccc(C)c1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1ccc2c(c1)C(C)(C)CCC2(C)C)C(C)(C)CCC3(C)C]

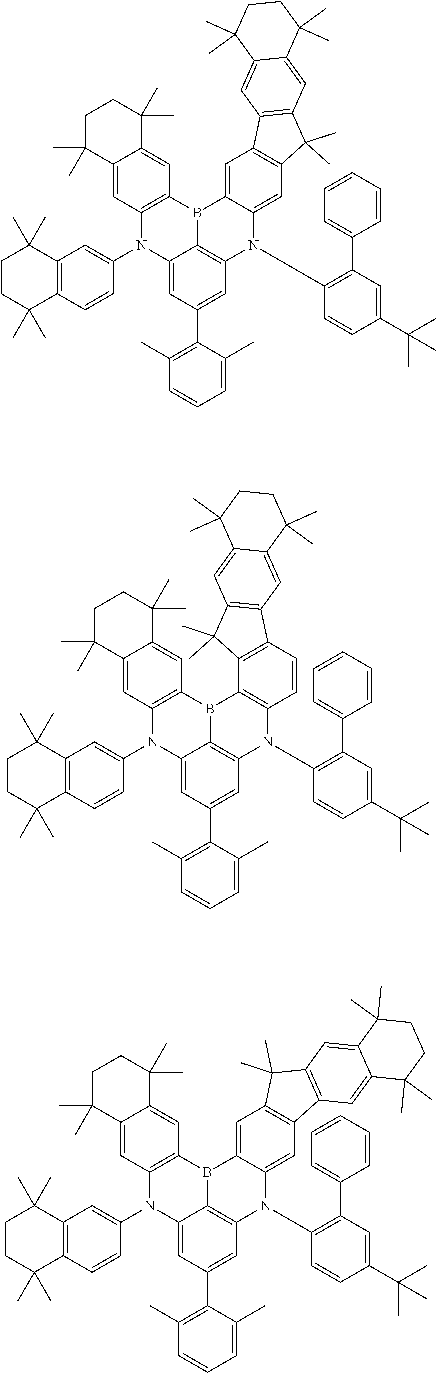 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)-c1cc2c(cc1C4(C)C)C(C)(C)CCC2(C)C ; Cc1cccc(C)c1-c1cc2c3c(c1)N(c1ccc(C(C)(C)C)cc1-c1ccccc1)c1ccc4c(c1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C]

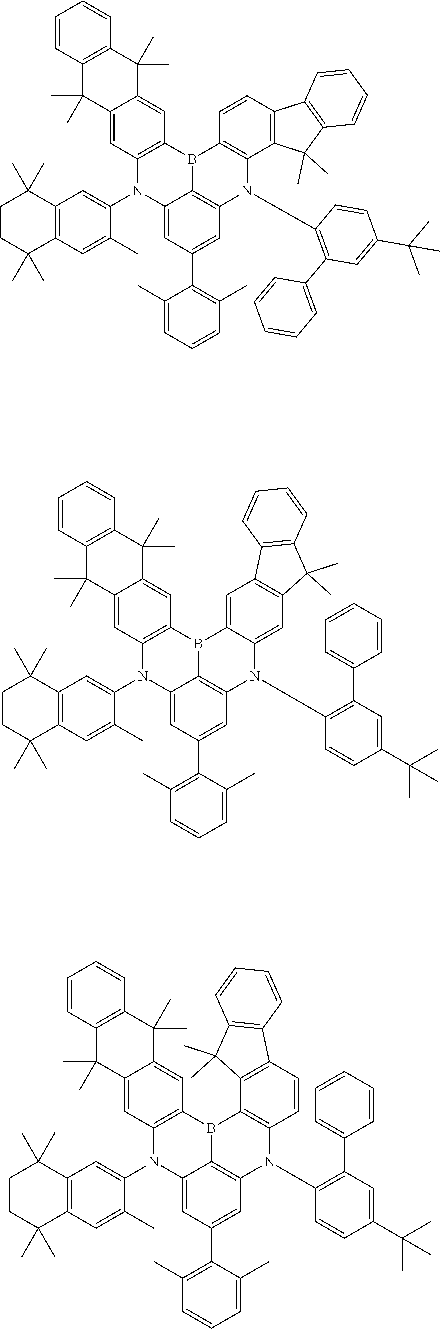 [SMILES: Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1ccccc1-6)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1ccccc1-6)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(c13)C(C)(C)c1ccccc1-5)C(C)(C)c1ccccc1C4(C)C)C(C)(C)CCC2(C)C]

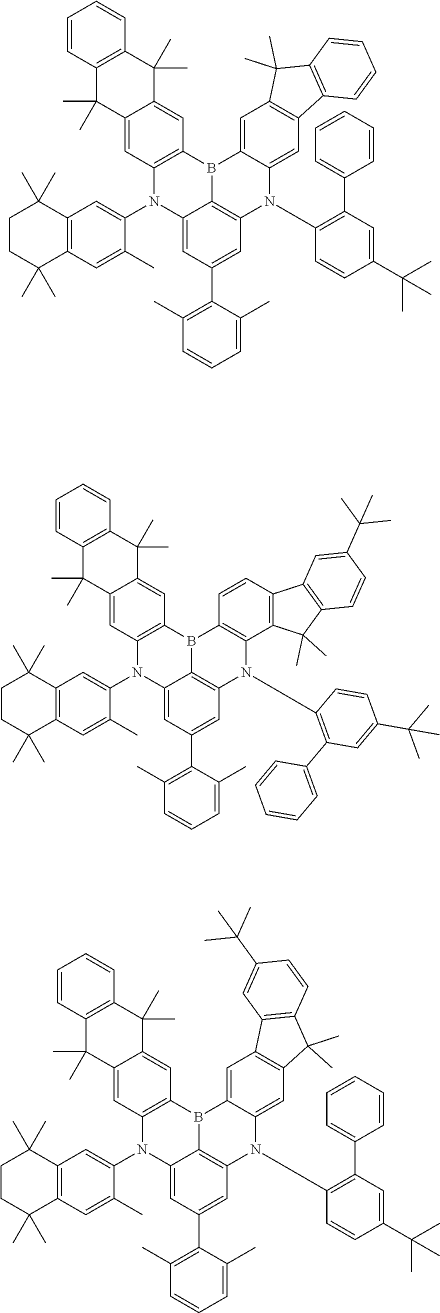 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)-c1ccccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1ccc(C(C)(C)C)cc1-6)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1ccc(C(C)(C)C)cc1-6)C(C)(C)c1ccccc1C4(C)C)C(C)(C)CCC2(C)C]

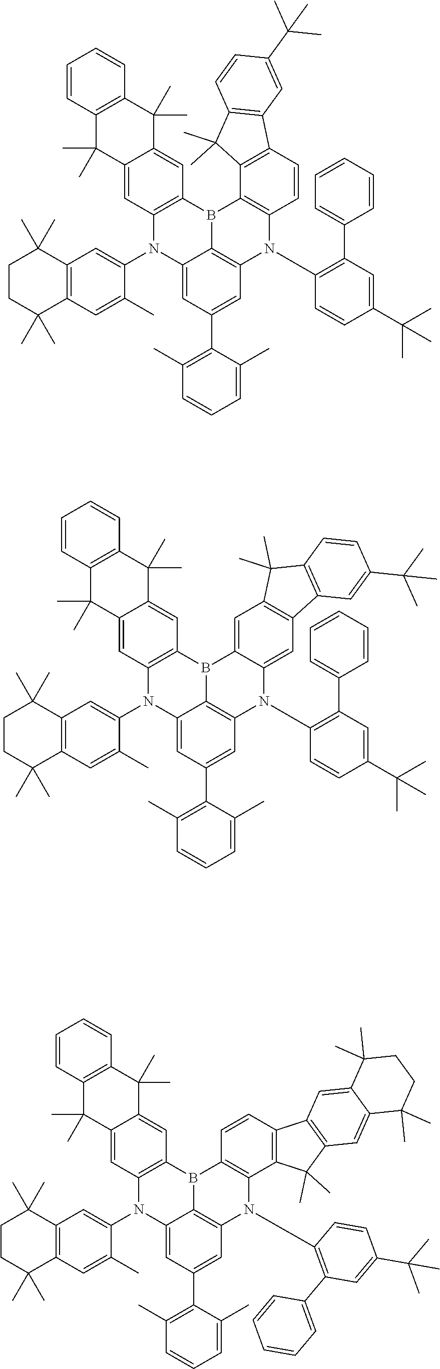 [SMILES: Cc1cc2c(cc1N1c3cc4c(cc3B3c5c1cc(-c1c(C)cccc1C)cc5N(c1ccc(C(C)(C)C)cc1-c1ccccc1)c1ccc5c(c13)C(C)(C)c1ccc(C(C)(C)C)cc1-5)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C]

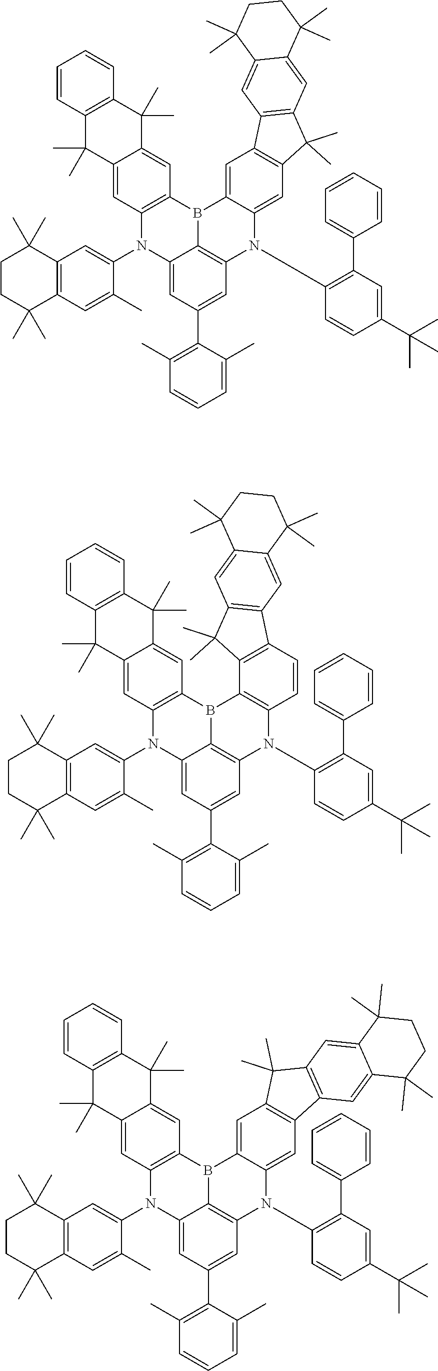 [SMILES: Cc1cc2c(cc1N1c3cc4c(cc3B3c5cc6c(cc5N(c5ccc(C(C)(C)C)cc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccc(C(C)(C)C)cc1-c1ccccc1)c1ccc5c(c13)C(C)(C)c1cc3c(cc1-5)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C]

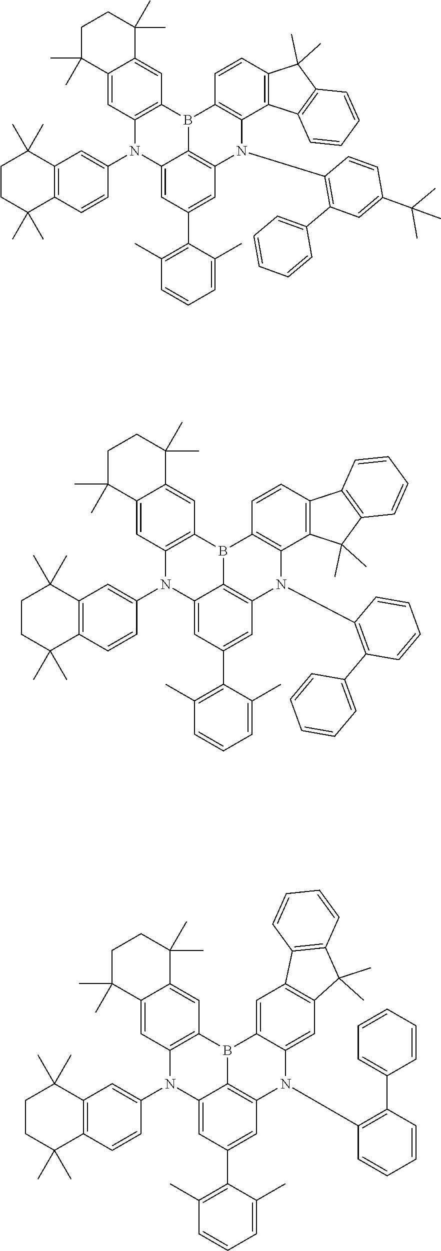 [SMILES: Cc1cccc(C)c1-c1cc2c3c(c1)N(c1ccc(C(C)(C)C)cc1-c1ccccc1)c1c(ccc4c1-c1ccccc1C4(C)C)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1c(ccc4c1C(C)(C)c1ccccc1-4)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)-c1ccccc1C4(C)C]

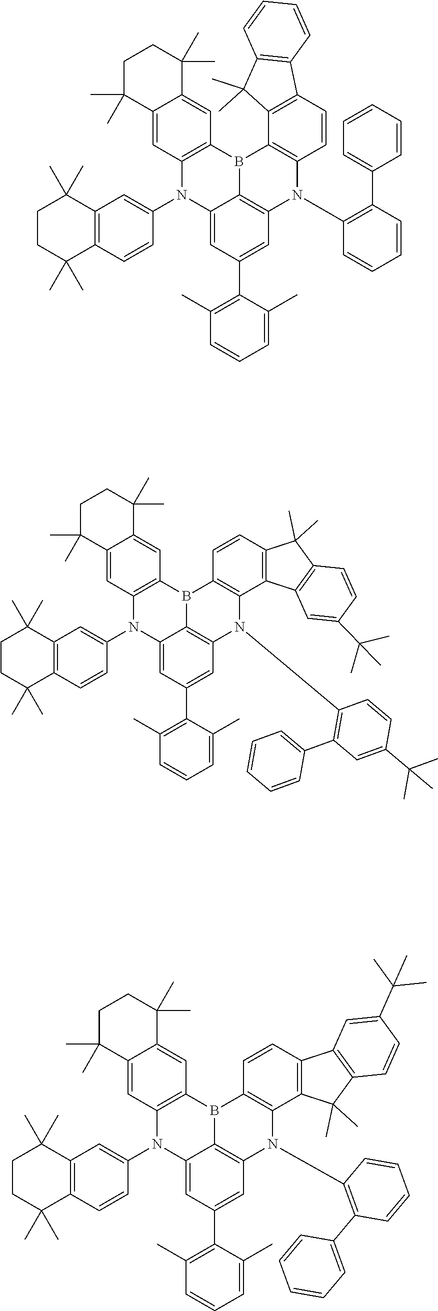 [SMILES: Cc1cccc(C)c1-c1cc2c3c(c1)N(c1ccccc1-c1ccccc1)c1ccc4c(c1B3c1cc3c(cc1N2c1ccc2c(c1)C(C)(C)CCC2(C)C)C(C)(C)CCC3(C)C)C(C)(C)c1ccccc1-4 ; Cc1cccc(C)c1-c1cc2c3c(c1)N(c1ccc(C(C)(C)C)cc1-c1ccccc1)c1c(ccc4c1-c1cc(C(C)(C)C)ccc1C4(C)C)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1c(ccc4c1C(C)(C)c1ccc(C(C)(C)C)cc1-4)B3c1cc3c(cc1N2c1ccc2c(c1)C(C)(C)CCC2(C)C)C(C)(C)CCC3(C)C]

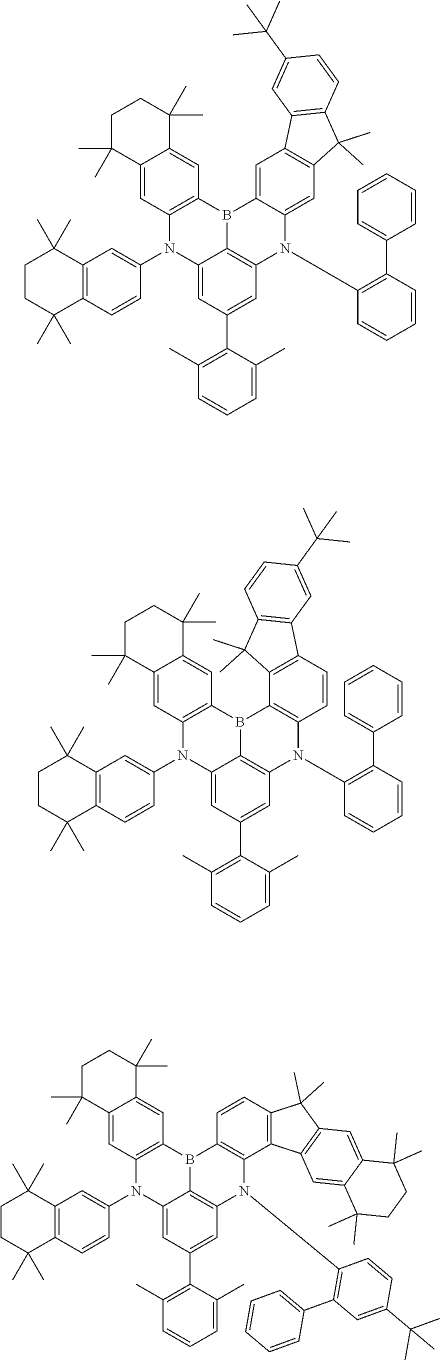 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)-c1cc(C(C)(C)C)ccc1C4(C)C ; Cc1cccc(C)c1-c1cc2c3c(c1)N(c1ccccc1-c1ccccc1)c1ccc4c(c1B3c1cc3c(cc1N2c1ccc2c(c1)C(C)(C)CCC2(C)C)C(C)(C)CCC3(C)C)C(C)(C)c1ccc(C(C)(C)C)cc1-4 ; Cc1cccc(C)c1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1ccc2c(c1)C(C)(C)CCC2(C)C)C(C)(C)CCC3(C)C]

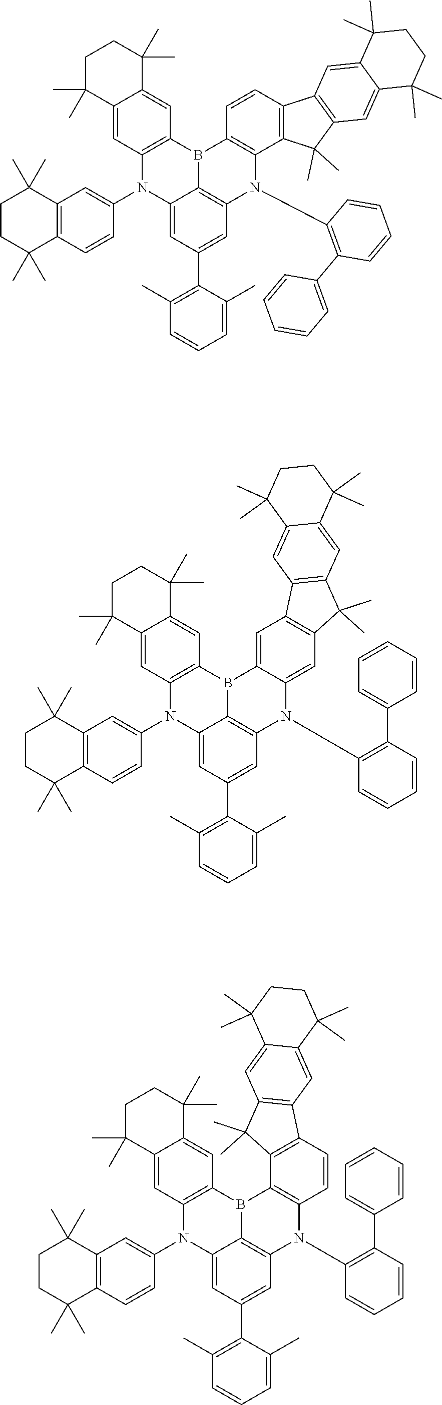 [SMILES: Cc1cccc(C)c1-c1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)-c1cc2c(cc1C4(C)C)C(C)(C)CCC2(C)C ; Cc1cccc(C)c1-c1cc2c3c(c1)N(c1ccccc1-c1ccccc1)c1ccc4c(c1B3c1cc3c(cc1N2c1ccc2c(c1)C(C)(C)CCC2(C)C)C(C)(C)CCC3(C)C)C(C)(C)c1cc2c(cc1-4)C(C)(C)CCC2(C)C]

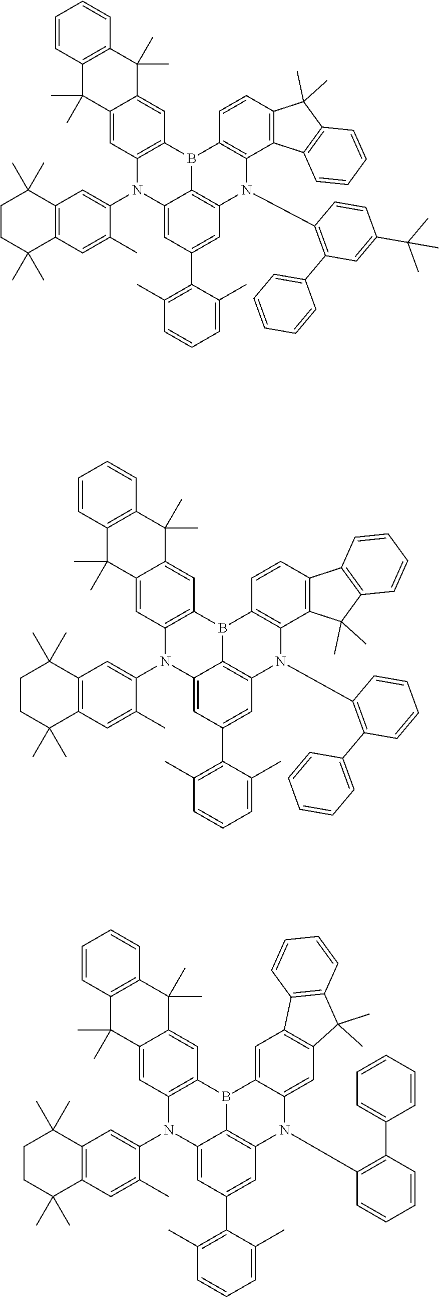 [SMILES: Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1ccccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1ccccc1-6)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)C(C)(C)c1ccccc1-6)C(C)(C)c1ccccc1C4(C)C)C(C)(C)CCC2(C)C]

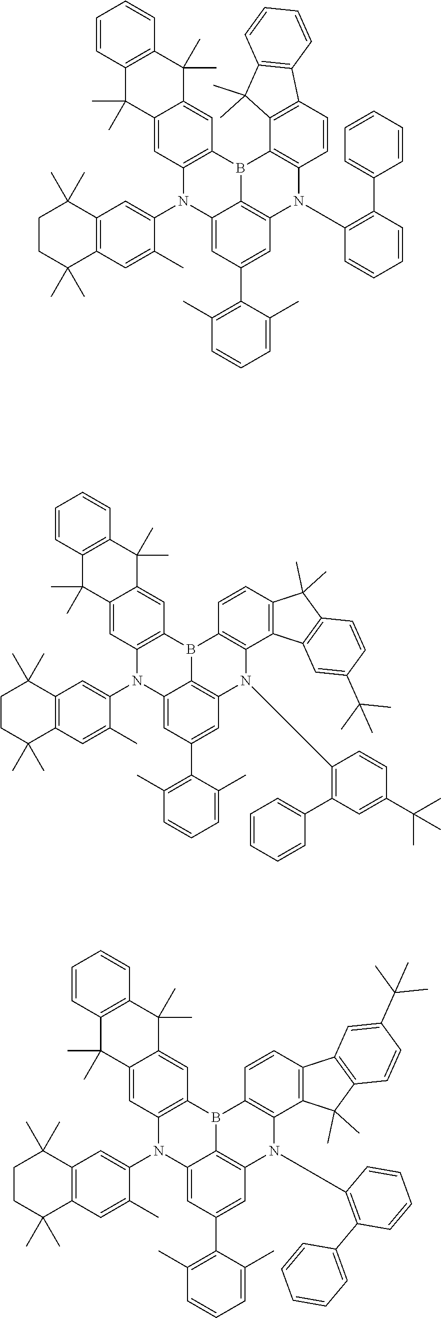 [SMILES: Cc1cc2c(cc1N1c3cc4c(cc3B3c5c1cc(-c1c(C)cccc1C)cc5N(c1ccccc1-c1ccccc1)c1ccc5c(c13)C(C)(C)c1ccccc1-5)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1ccc(C(C)(C)C)cc1-6)C(C)(C)c1ccccc1C4(C)C)C(C)(C)CCC2(C)C]

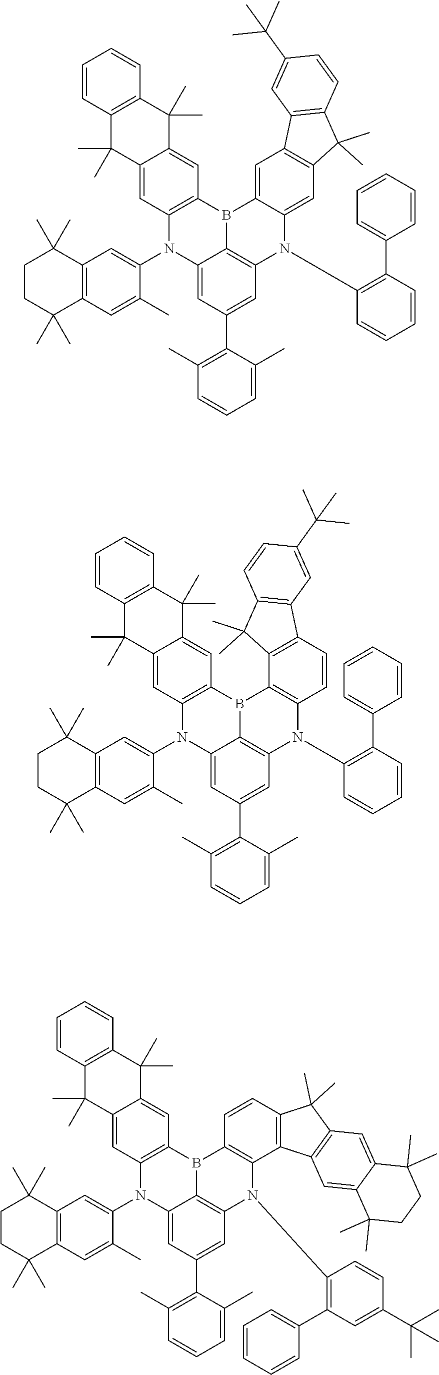 [SMILES: Cc1cc2c(cc1N1c3cc4c(cc3B3c5cc6c(cc5N(c5ccccc5-c5ccccc5)c5cc(-c7c(C)cccc7C)cc1c53)C(C)(C)c1ccc(C(C)(C)C)cc1-6)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(c13)C(C)(C)c1ccc(C(C)(C)C)cc1-5)C(C)(C)c1ccccc1C4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C]

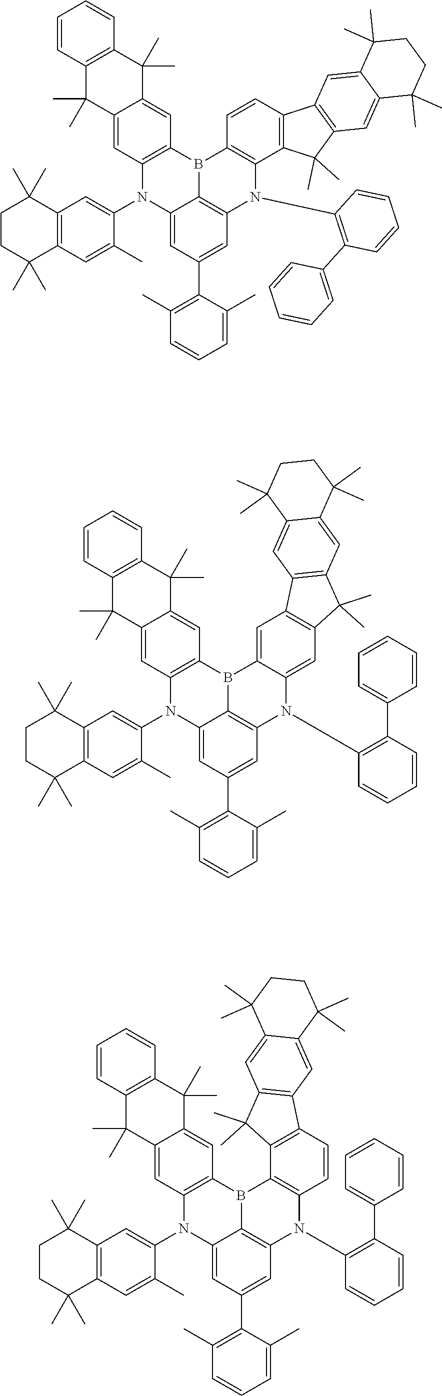 [SMILES: Cc1cc2c(cc1N1c3cc4c(cc3B3c5ccc6c(c5N(c5ccccc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(c13)C(C)(C)c1cc3c(cc1-5)C(C)(C)CCC3(C)C)C(C)(C)c1ccccc1C4(C)C)C(C)(C)CCC2(C)C]

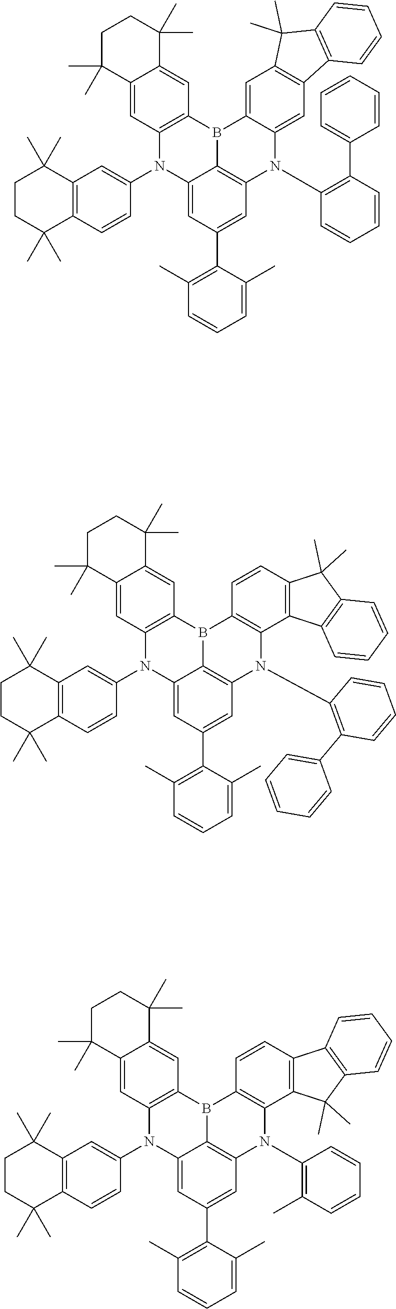 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)C(C)(C)c1ccccc1-4 ; Cc1cccc(C)c1-c1cc2c3c(c1)N(c1ccccc1-c1ccccc1)c1c(ccc4c1-c1ccccc1C4(C)C)B3c1cc3c(cc1N2c1ccc2c(c1)C(C)(C)CCC2(C)C)C(C)(C)CCC3(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(c21)C(C)(C)c1ccccc1-3]

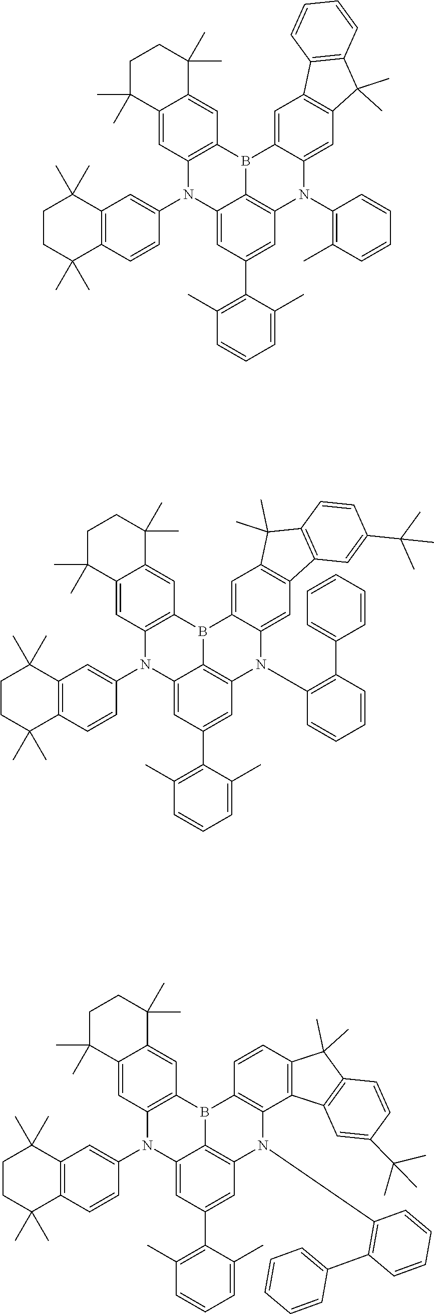 [SMILES: Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)-c1ccccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)CCC2(C)C)C(C)(C)CCC3(C)C)C(C)(C)c1ccc(C(C)(C)C)cc1-4 ; Cc1cccc(C)c1-c1cc2c3c(c1)N(c1ccccc1-c1ccccc1)c1c(ccc4c1-c1cc(C(C)(C)C)ccc1C4(C)C)B3c1cc3c(cc1N2c1ccc2c(c1)C(C)(C)CCC2(C)C)C(C)(C)CCC3(C)C]

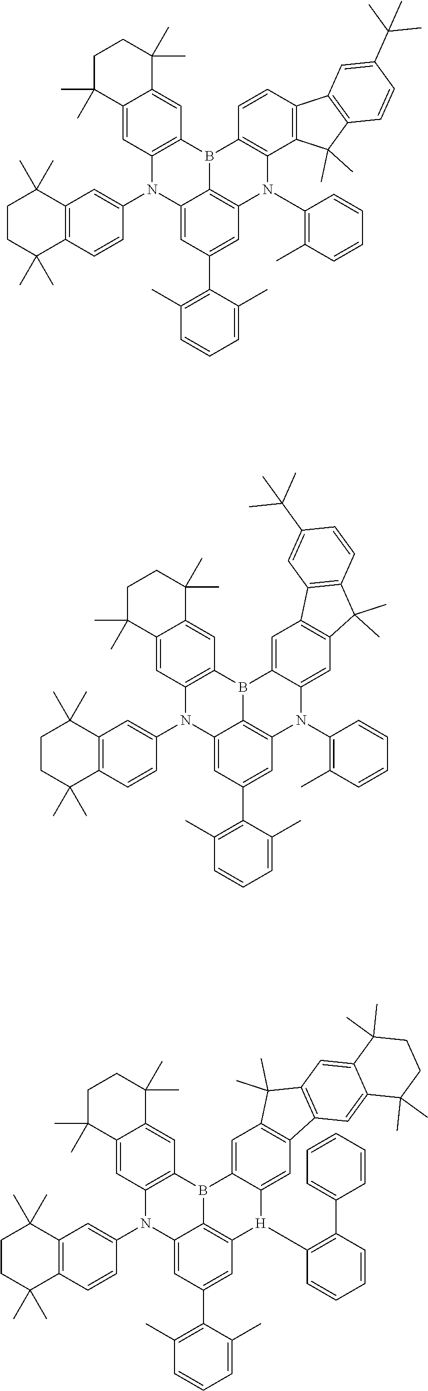

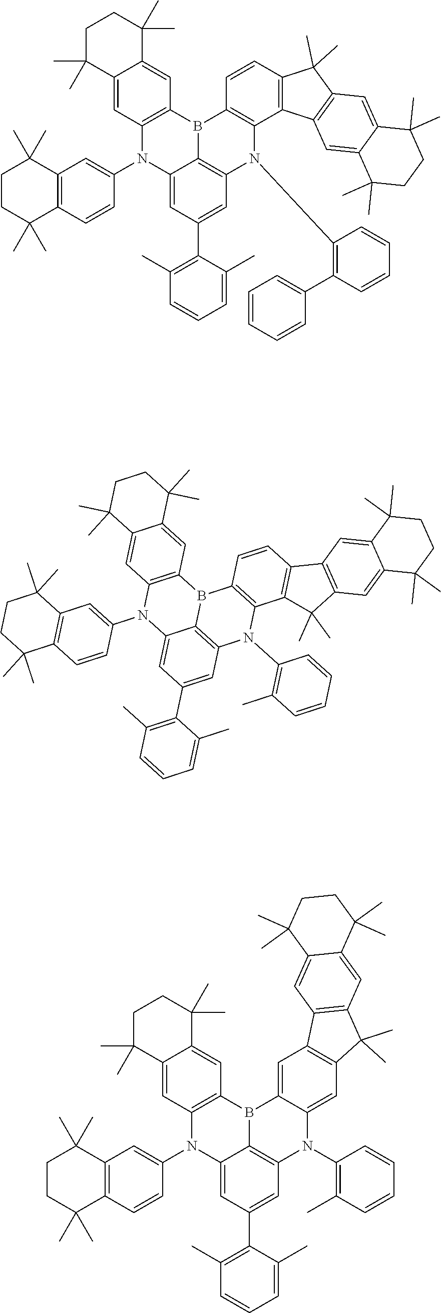 [SMILES: Cc1cccc(C)c1-c1cc2c3c(c1)N(c1ccccc1-c1ccccc1)c1c(ccc4c1-c1cc5c(cc1C4(C)C)C(C)(C)CCC5(C)C)B3c1cc3c(cc1N2c1ccc2c(c1)C(C)(C)CCC2(C)C)C(C)(C)CCC3(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(c21)C(C)(C)c1cc2c(cc1-3)C(C)(C)CCC2(C)C ; Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)-c1cc2c(cc1C3(C)C)C(C)(C)CCC2(C)C]

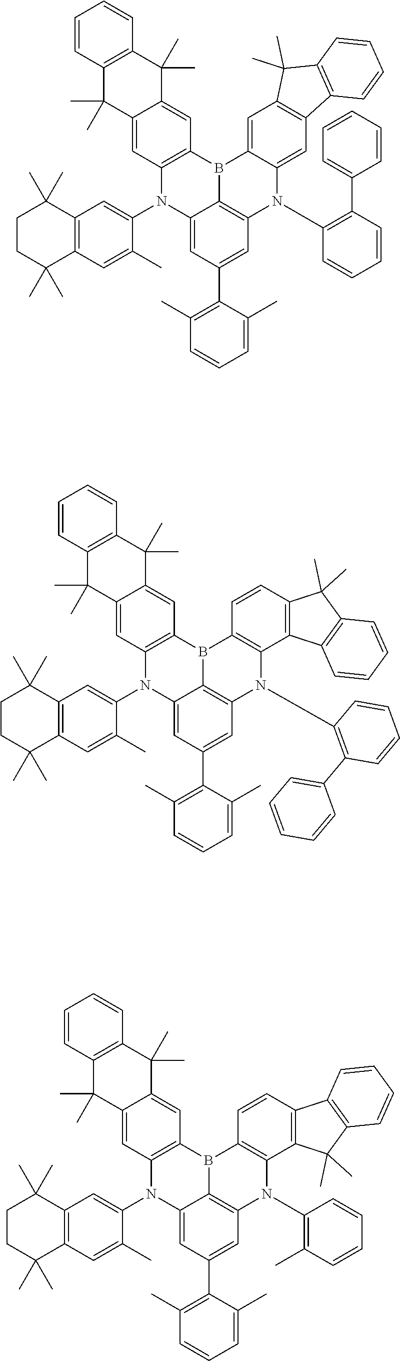 [SMILES: Cc1cc2c(cc1N1c3cc4c(cc3B3c5cc6c(cc5N(c5ccccc5-c5ccccc5)c5cc(-c7c(C)cccc7C)cc1c53)-c1ccccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)-c1ccccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5C)c5cc(-c7c(C)cccc7C)cc1c53)C(C)(C)c1ccccc1-6)C(C)(C)c1ccccc1C4(C)C)C(C)(C)CCC2(C)C]

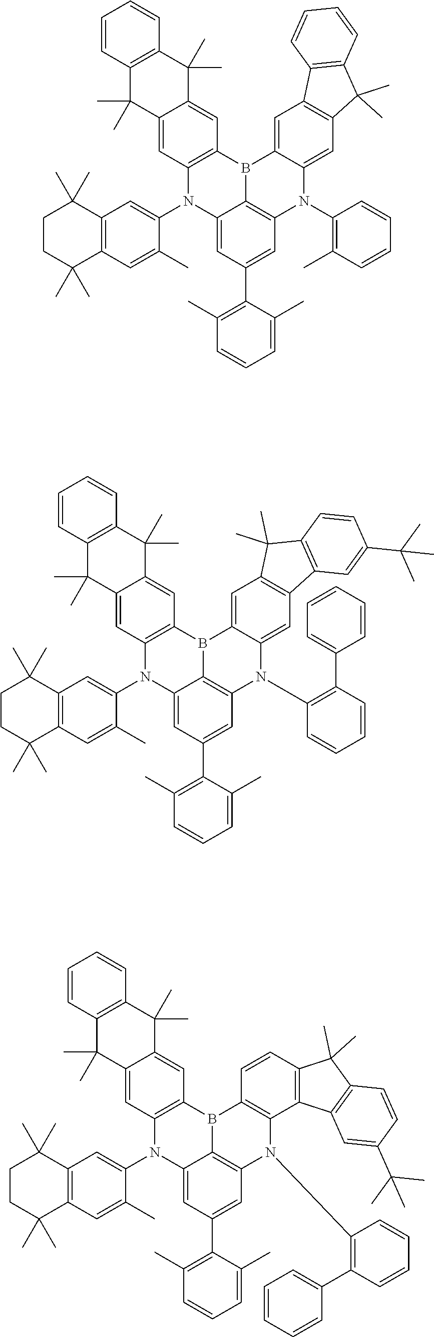 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)-c1ccccc1C3(C)C ; Cc1cc2c(cc1N1c3cc4c(cc3B3c5cc6c(cc5N(c5ccccc5-c5ccccc5)c5cc(-c7c(C)cccc7C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)-c1cc(C(C)(C)C)ccc1C6(C)C)C(C)(C)c1ccccc1C4(C)C)C(C)(C)CCC2(C)C]

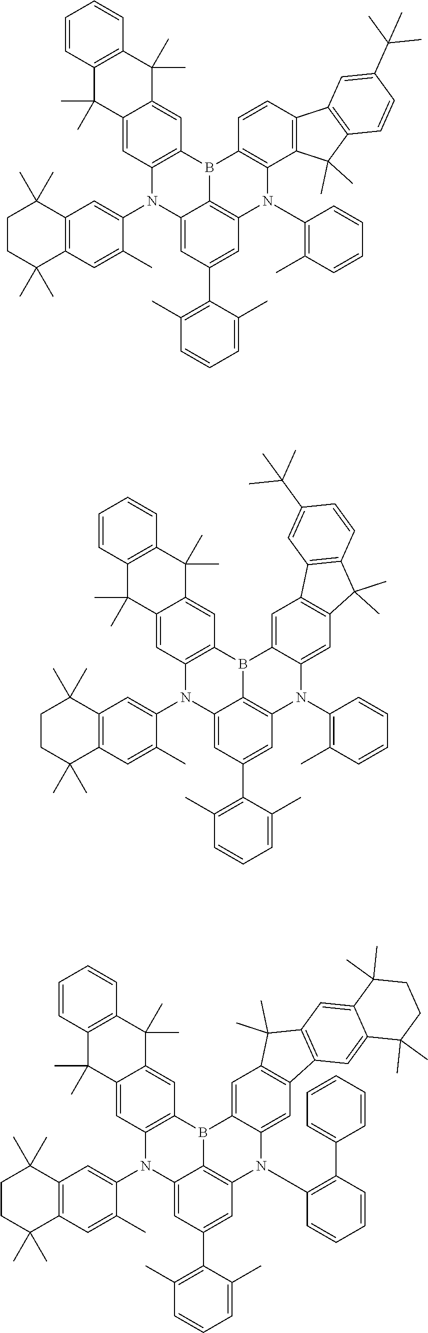 [SMILES: Cc1cc2c(cc1N1c3cc4c(cc3B3c5ccc6c(c5N(c5ccccc5C)c5cc(-c7c(C)cccc7C)cc1c53)C(C)(C)c1ccc(C(C)(C)C)cc1-6)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)-c1cc(C(C)(C)C)ccc1C3(C)C ; Cc1cc2c(cc1N1c3cc4c(cc3B3c5cc6c(cc5N(c5ccccc5-c5ccccc5)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C]

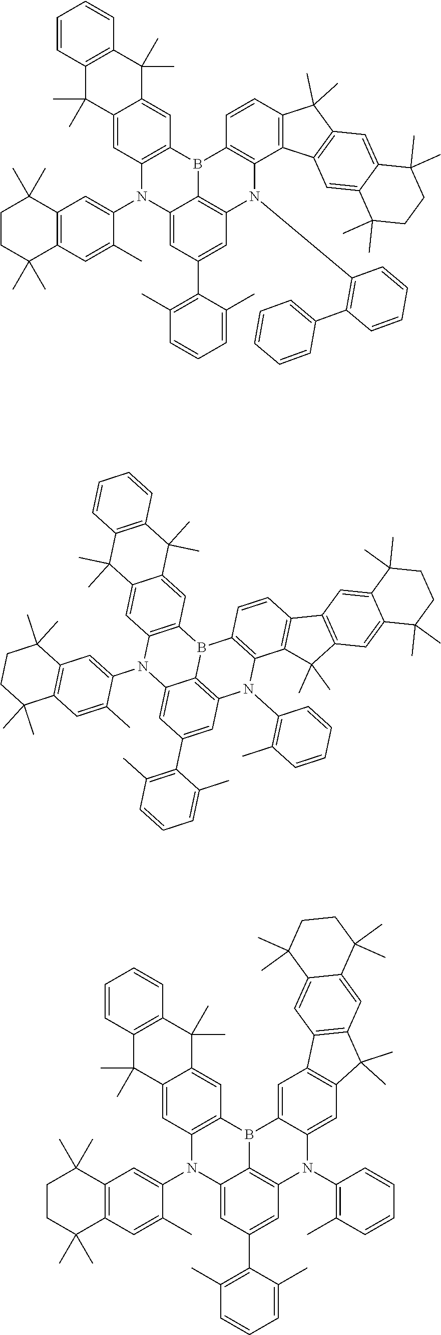 [SMILES: Cc1cc2c(cc1N1c3cc4c(cc3B3c5ccc6c(c5N(c5ccccc5-c5ccccc5)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5ccccc5C)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)-c1cc2c(cc1C3(C)C)C(C)(C)CCC2(C)C]

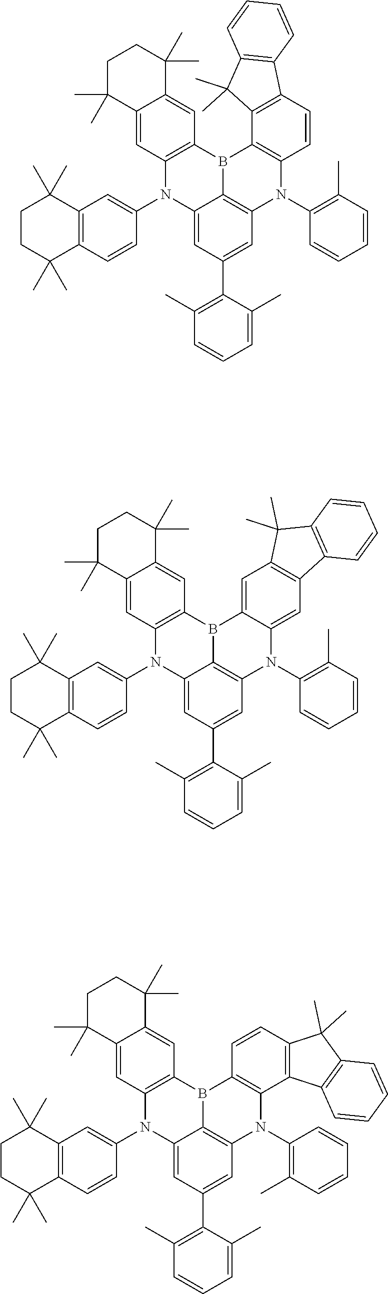 [SMILES: Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2c1ccc1c2C(C)(C)c2ccccc2-1 ; Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)C(C)(C)c1ccccc1-3 ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(c21)-c1ccccc1C3(C)C]

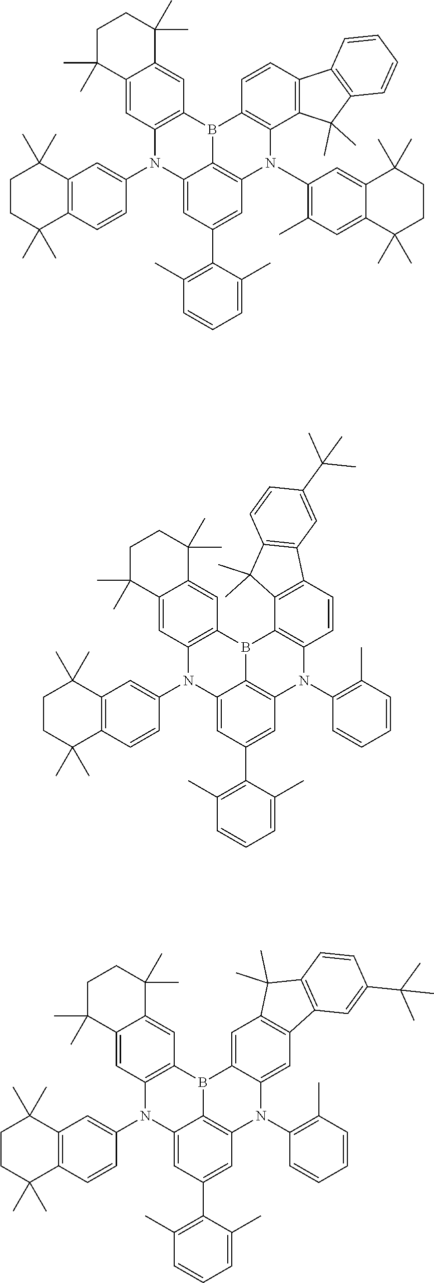 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(c31)C(C)(C)c1ccccc1-4)C(C)(C)CCC2(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2c1ccc1c2C(C)(C)c2ccc(C(C)(C)C)cc2-1 ; Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)C(C)(C)c1ccc(C(C)(C)C)cc1-3]

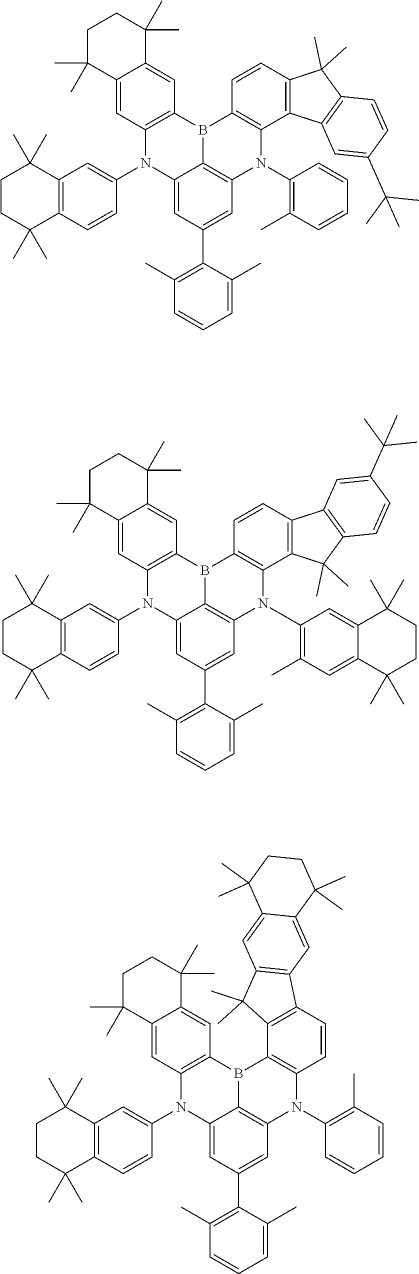 [SMILES: Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(c21)-c1cc(C(C)(C)C)ccc1C3(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(c31)C(C)(C)c1ccc(C(C)(C)C)cc1-4)C(C)(C)CCC2(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2c1ccc1c2C(C)(C)c2cc3c(cc2-1)C(C)(C)CCC3(C)C]

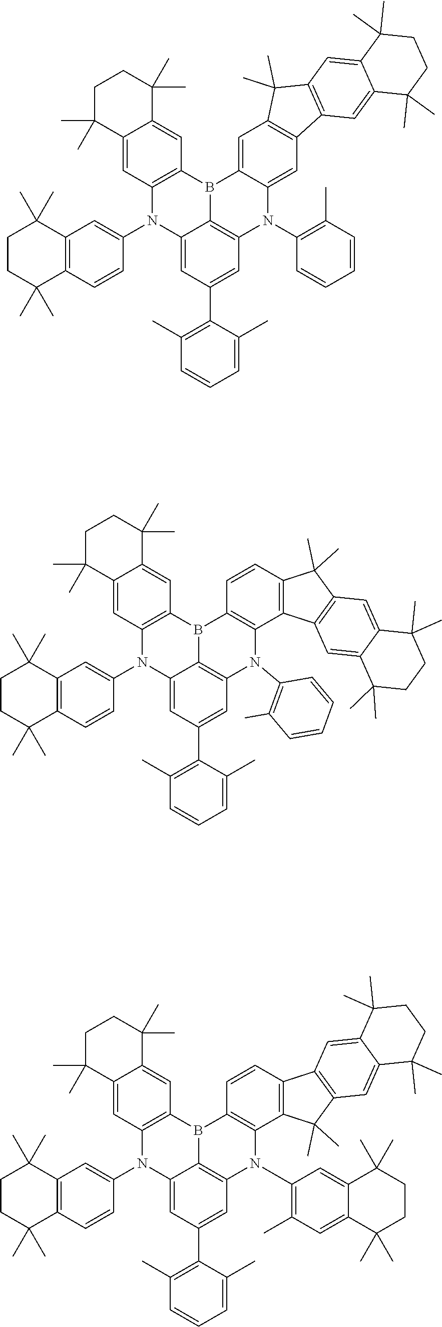 [SMILES: Cc1ccccc1N1c2cc3c(cc2B2c4cc5c(cc4N(c4ccc6c(c4)C(C)(C)CCC6(C)C)c4cc(-c6c(C)cccc6C)cc1c42)C(C)(C)CCC5(C)C)C(C)(C)c1cc2c(cc1-3)C(C)(C)CCC2(C)C ; Cc1ccccc1N1c2cc(-c3c(C)cccc3C)cc3c2B(c2cc4c(cc2N3c2ccc3c(c2)C(C)(C)CCC3(C)C)C(C)(C)CCC4(C)C)c2ccc3c(c21)-c1cc2c(cc1C3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(c31)C(C)(C)c1cc3c(cc1-4)C(C)(C)CCC3(C)C)C(C)(C)CCC2(C)C]

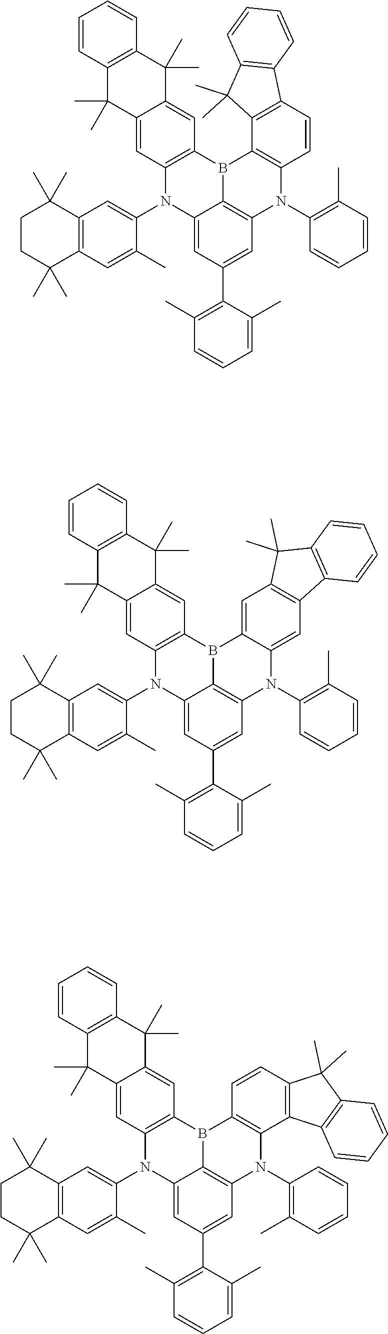 [SMILES: Cc1cc2c(cc1N1c3cc4c(cc3B3c5c1cc(-c1c(C)cccc1C)cc5N(c1ccccc1C)c1ccc5c(c13)C(C)(C)c1ccccc1-5)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)C(C)(C)c1ccccc1-3 ; Cc1cc2c(cc1N1c3cc4c(cc3B3c5ccc6c(c5N(c5ccccc5C)c5cc(-c7c(C)cccc7C)cc1c53)-c1ccccc1C6(C)C)C(C)(C)c1ccccc1C4(C)C)C(C)(C)CCC2(C)C]

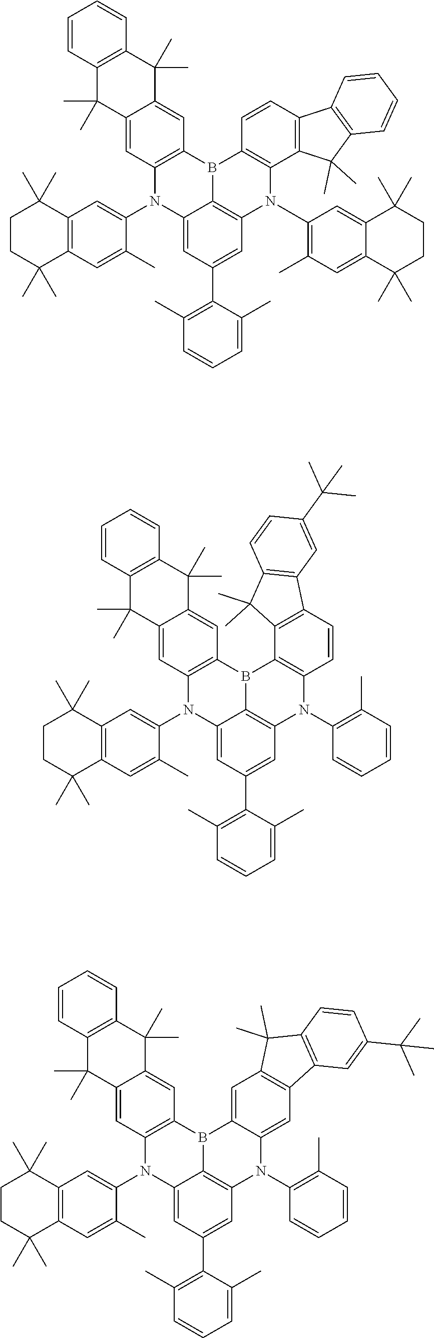 [SMILES: Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)C(C)(C)c1ccccc1-6)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(c13)C(C)(C)c1ccc(C(C)(C)C)cc1-5)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)C(C)(C)c1ccc(C(C)(C)C)cc1-3]

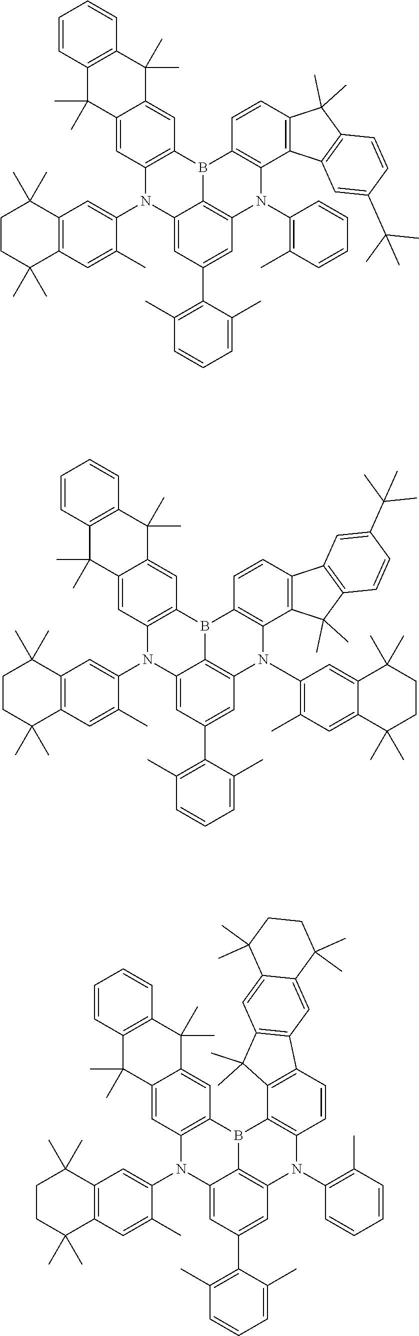 [SMILES: Cc1cc2c(cc1N1c3cc4c(cc3B3c5ccc6c(c5N(c5ccccc5C)c5cc(-c7c(C)cccc7C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)C(C)(C)c1ccc(C(C)(C)C)cc1-6)C(C)(C)c1ccccc1C4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(c13)C(C)(C)c1cc3c(cc1-5)C(C)(C)CCC3(C)C)C(C)(C)c1ccccc1C4(C)C)C(C)(C)CCC2(C)C]

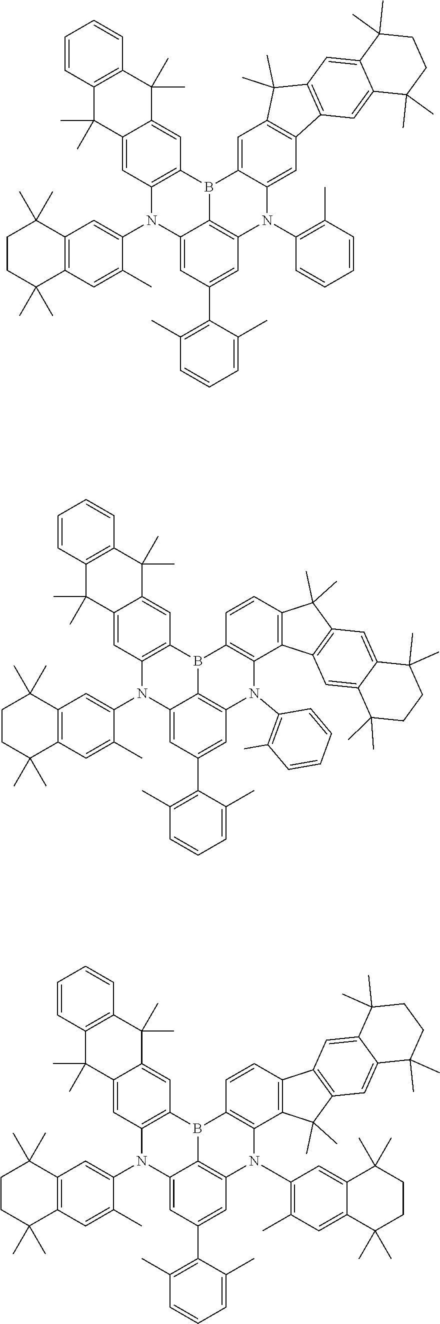 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)c1ccccc1C5(C)C)C(C)(C)c1cc2c(cc1-3)C(C)(C)CCC2(C)C ; Cc1cc2c(cc1N1c3cc4c(cc3B3c5ccc6c(c5N(c5ccccc5C)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)C(C)(C)c1cc3c(cc1-6)C(C)(C)CCC3(C)C)C(C)(C)c1ccccc1C4(C)C)C(C)(C)CCC2(C)C]

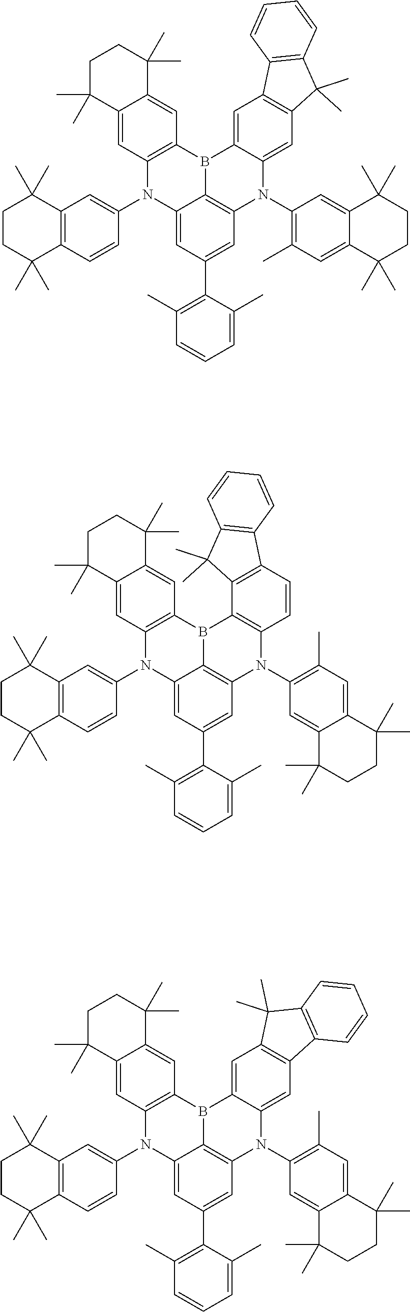 [SMILES: Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)-c1ccccc1C4(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3C(C)(C)c3ccccc3-1)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)C(C)(C)c1ccccc1-4)C(C)(C)CCC2(C)C]

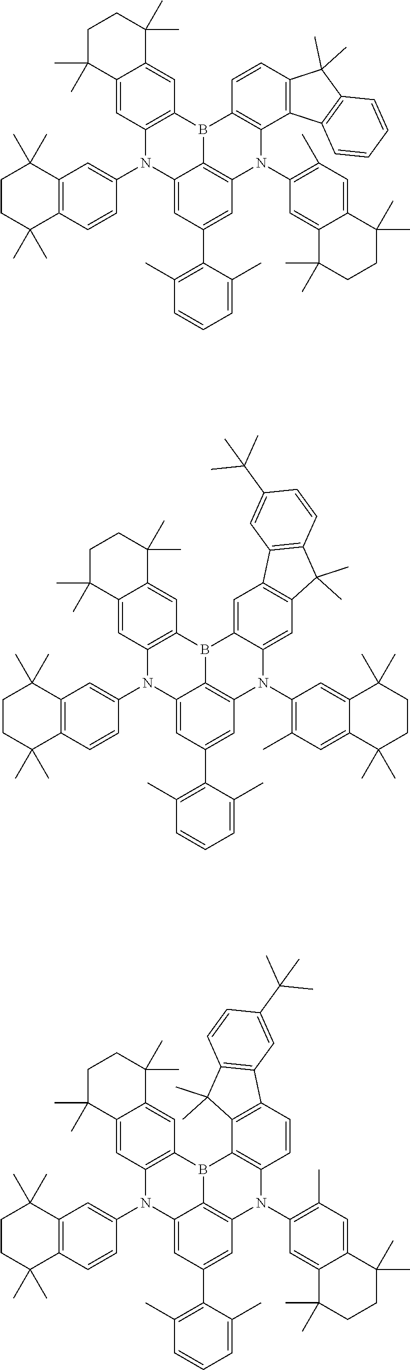 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(c31)-c1ccccc1C4(C)C)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)-c1cc(C(C)(C)C)ccc1C4(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3C(C)(C)c3ccc(C(C)(C)C)cc3-1)C(C)(C)CCC2(C)C]

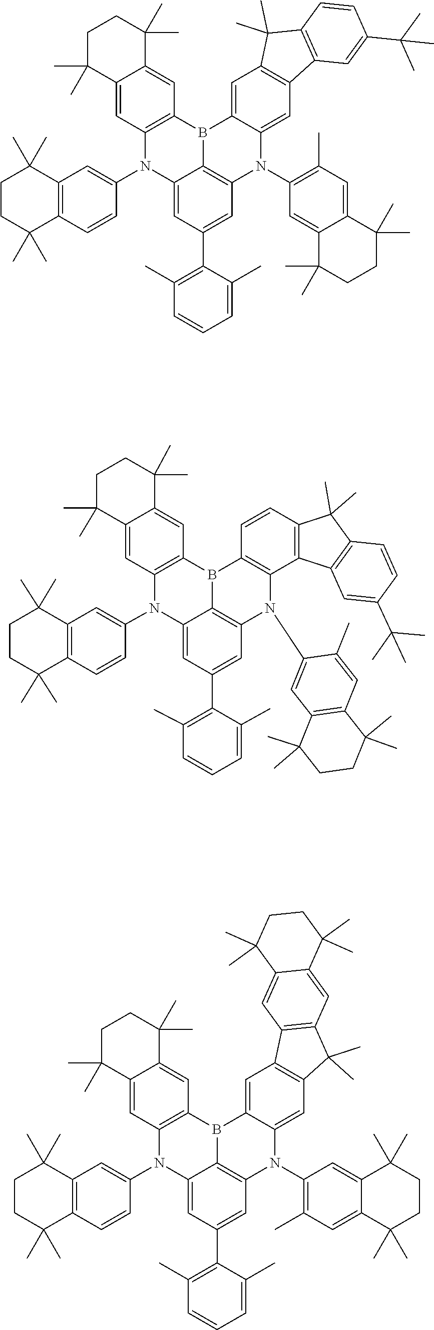 [SMILES: Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)C(C)(C)c1ccc(C(C)(C)C)cc1-4)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(c31)-c1cc(C(C)(C)C)ccc1C4(C)C)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)-c1cc3c(cc1C4(C)C)C(C)(C)CCC3(C)C)C(C)(C)CCC2(C)C]

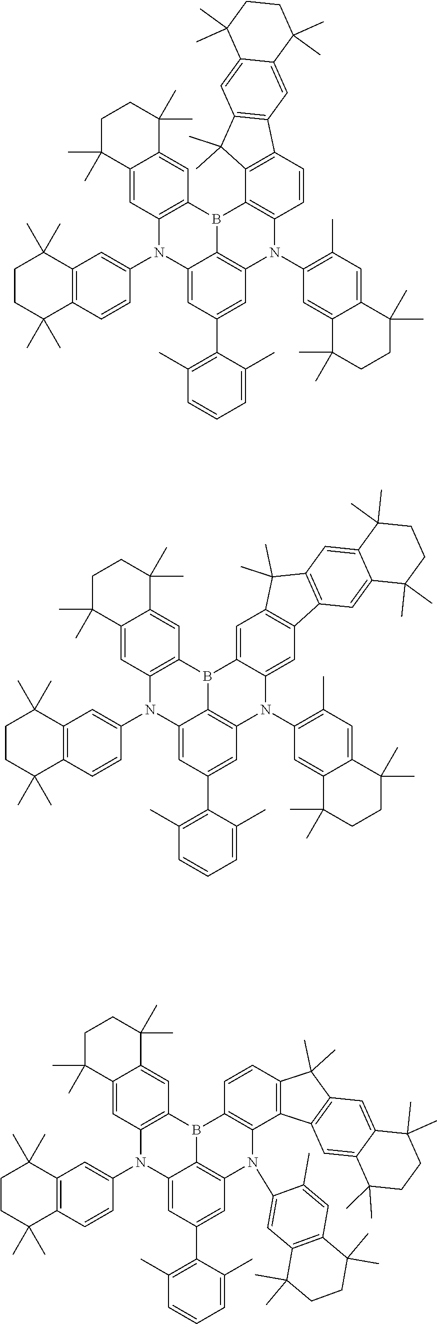 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3C(C)(C)c3cc4c(cc3-1)C(C)(C)CCC4(C)C)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)C(C)(C)c1cc3c(cc1-4)C(C)(C)CCC3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(c31)-c1cc3c(cc1C4(C)C)C(C)(C)CCC3(C)C)C(C)(C)CCC2(C)C]

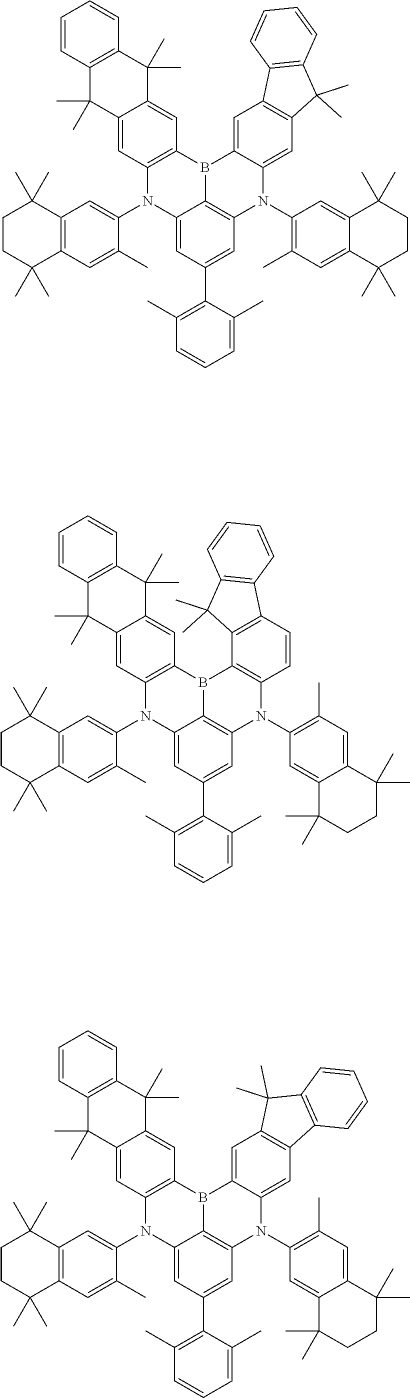 [SMILES: Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)-c1ccccc1C4(C)C)C(C)(C)CCC2(C)C ; Cc1cc2c(cc1N1c3cc4c(cc3B3c5c1cc(-c1c(C)cccc1C)cc5N(c1cc5c(cc1C)C(C)(C)CCC5(C)C)c1ccc5c(c13)C(C)(C)c1ccccc1-5)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)C(C)(C)c1ccccc1-4)C(C)(C)CCC2(C)C]

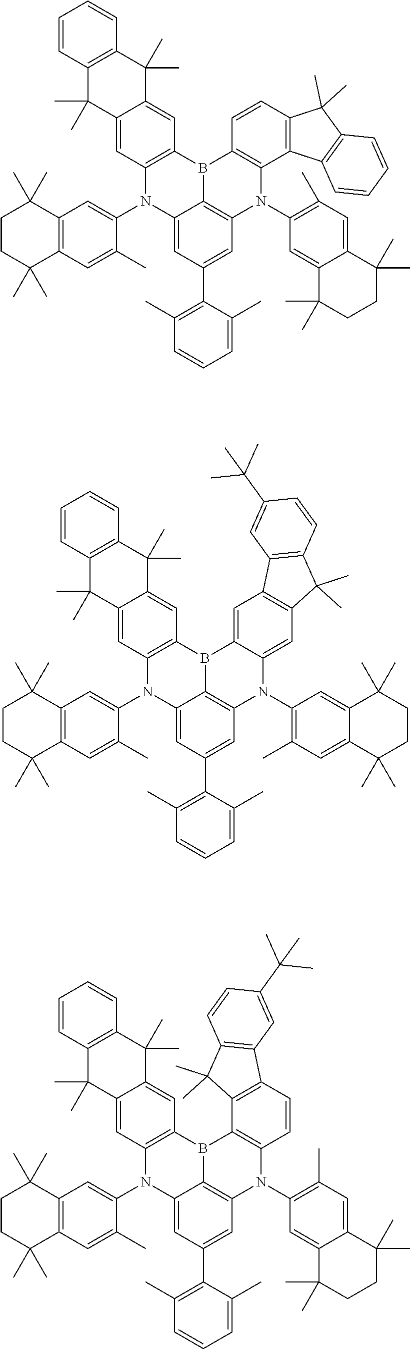 [SMILES: Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)-c1ccccc1C6(C)C)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)-c1cc(C(C)(C)C)ccc1C4(C)C)C(C)(C)CCC2(C)C ; Cc1cc2c(cc1N1c3cc4c(cc3B3c5c1cc(-c1c(C)cccc1C)cc5N(c1cc5c(cc1C)C(C)(C)CCC5(C)C)c1ccc5c(c13)C(C)(C)c1ccc(C(C)(C)C)cc1-5)C(C)(C)c1ccccc1C4(C)C)C(C)(C)CCC2(C)C]

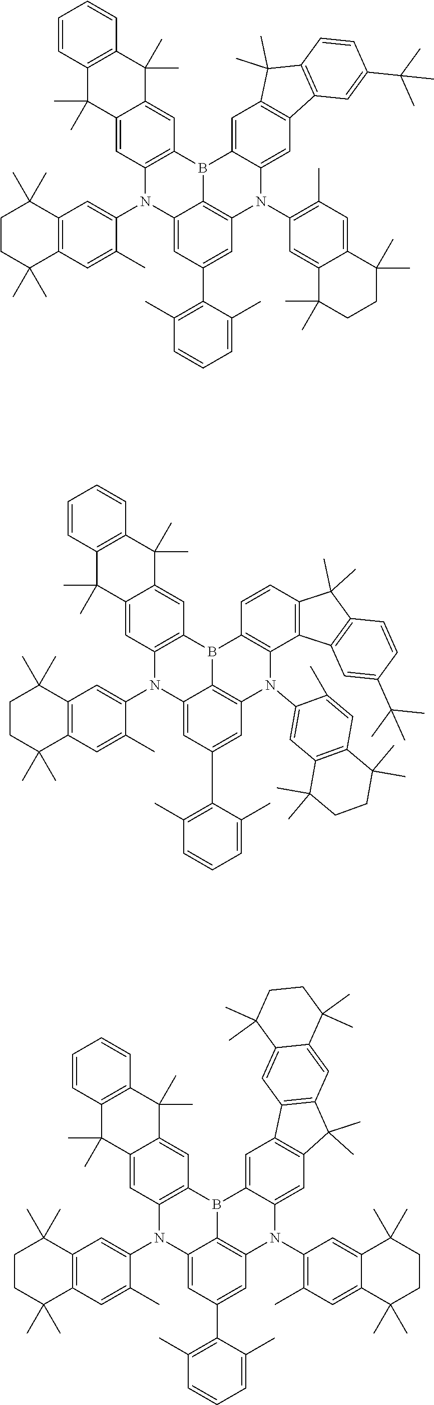 [SMILES: Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)C(C)(C)c1ccc(C(C)(C)C)cc1-4)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)-c1cc(C(C)(C)C)ccc1C6(C)C)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)-c1cc3c(cc1C4(C)C)C(C)(C)CCC3(C)C)C(C)(C)CCC2(C)C]

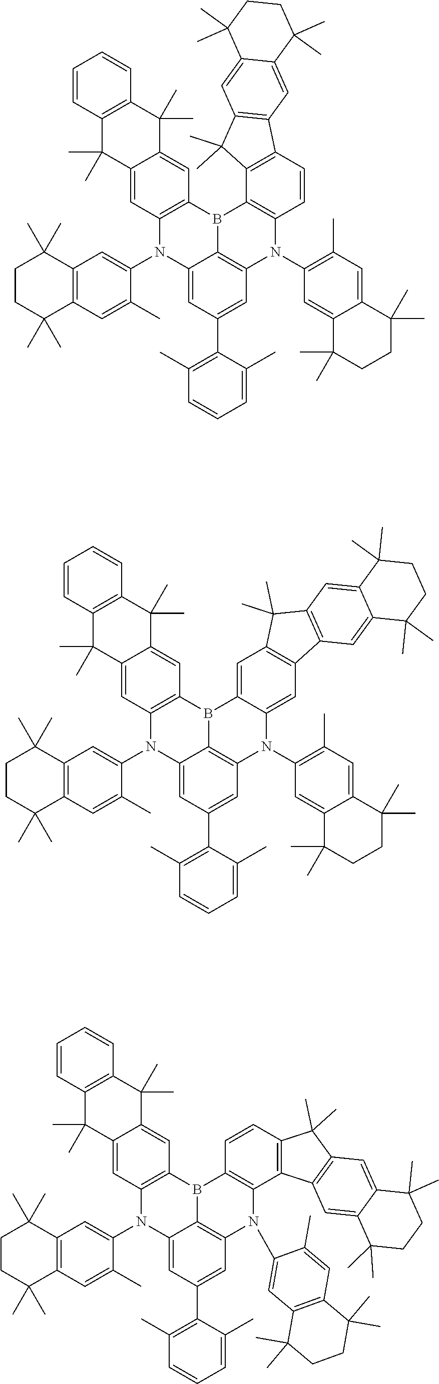 [SMILES: Cc1cc2c(cc1N1c3cc4c(cc3B3c5c1cc(-c1c(C)cccc1C)cc5N(c1cc5c(cc1C)C(C)(C)CCC5(C)C)c1ccc5c(c13)C(C)(C)c1cc3c(cc1-5)C(C)(C)CCC3(C)C)C(C)(C)c1ccccc1C4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)C(C)(C)c1ccccc1C6(C)C)C(C)(C)c1cc3c(cc1-4)C(C)(C)CCC3(C)C)C(C)(C)CCC2(C)C ; Cc1cc2c(cc1N1c3cc4c(cc3B3c5ccc6c(c5N(c5cc7c(cc5C)C(C)(C)CCC7(C)C)c5cc(-c7c(C)cccc7C)cc1c53)-c1cc3c(cc1C6(C)C)C(C)(C)CCC3(C)C)C(C)(C)c1ccccc1C4(C)C)C(C)(C)CCC2(C)C]

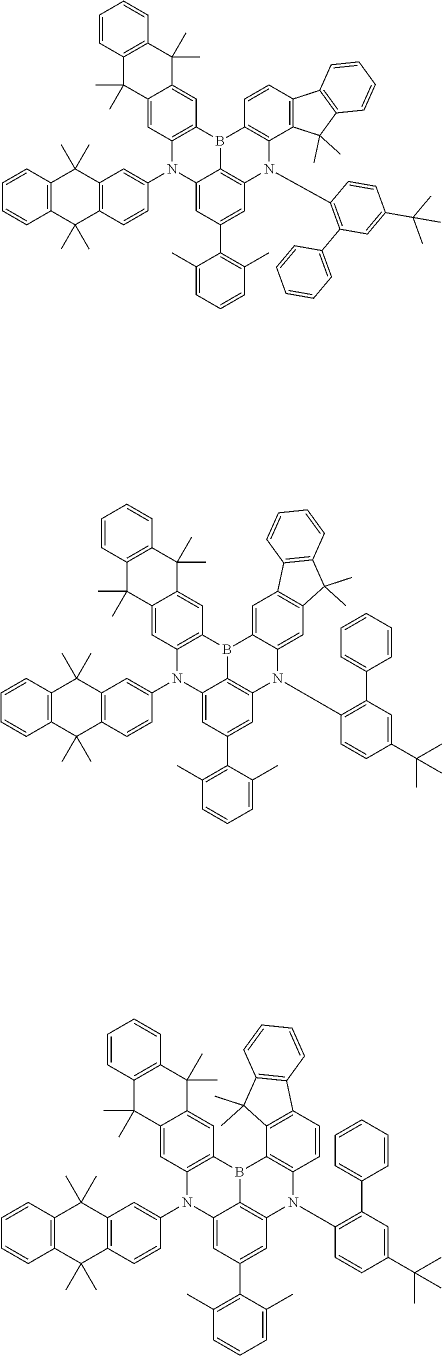 [SMILES: Cc1cccc(C)c1-c1cc2c3c(c1)N(c1ccc(C(C)(C)C)cc1-c1ccccc1)c1c(ccc4c1C(C)(C)c1ccccc1-4)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)-c1ccccc1C4(C)C ; Cc1cccc(C)c1-c1cc2c3c(c1)N(c1ccc(C(C)(C)C)cc1-c1ccccc1)c1ccc4c(c1B3c1cc3c(cc1N2c1ccc2c(c1)C(C)(C)c1ccccc1C2(C)C)C(C)(C)c1ccccc1C3(C)C)C(C)(C)c1ccccc1-4]

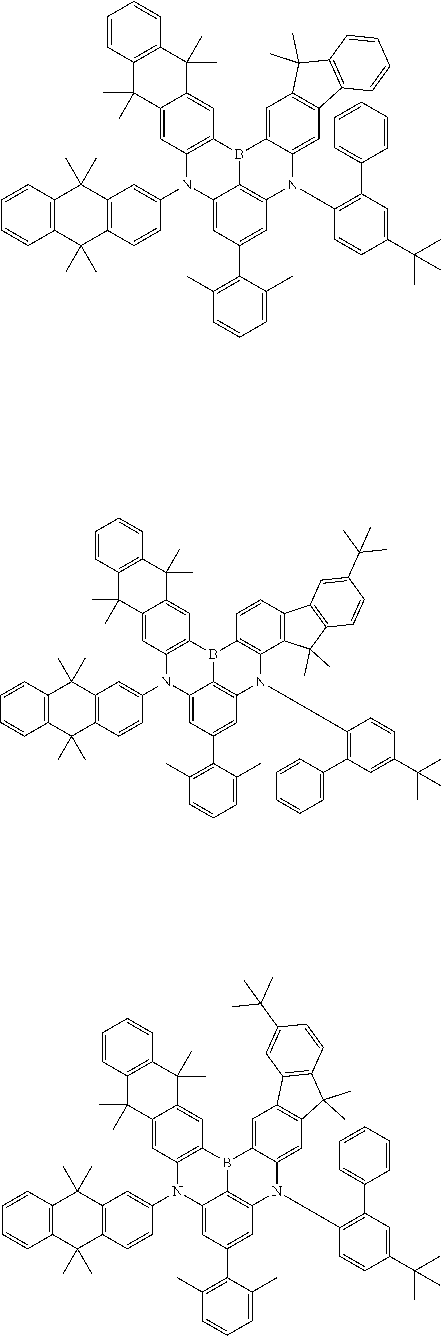 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1-4 ; Cc1cccc(C)c1-c1cc2c3c(c1)N(c1ccc(C(C)(C)C)cc1-c1ccccc1)c1c(ccc4c1C(C)(C)c1ccc(C(C)(C)C)cc1-4)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)-c1cc(C(C)(C)C)ccc1C4(C)C]

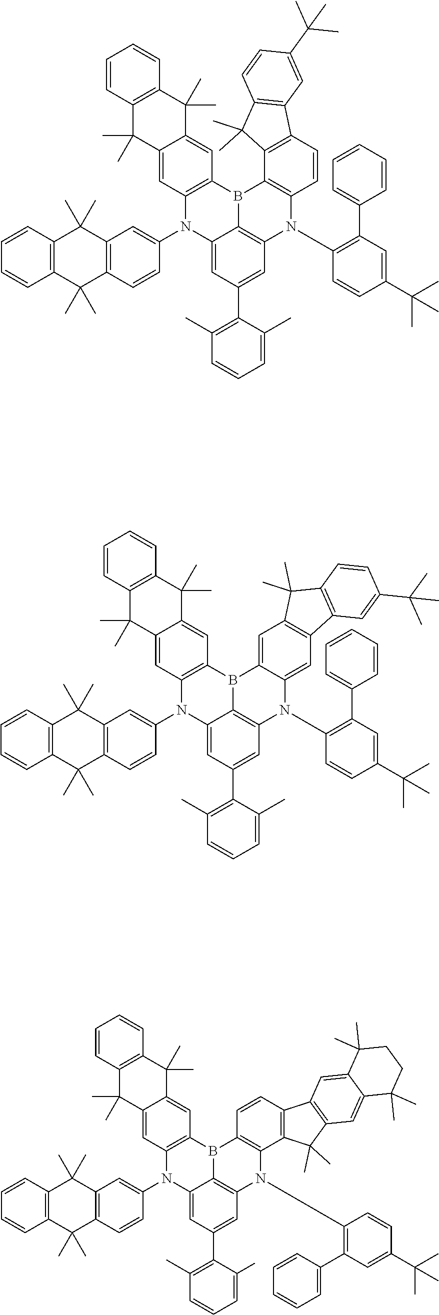 [SMILES: Cc1cccc(C)c1-c1cc2c3c(c1)N(c1ccc(C(C)(C)C)cc1-c1ccccc1)c1ccc4c(c1B3c1cc3c(cc1N2c1ccc2c(c1)C(C)(C)c1ccccc1C2(C)C)C(C)(C)c1ccccc1C3(C)C)C(C)(C)c1ccc(C(C)(C)C)cc1-4 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1ccc(C(C)(C)C)cc1-4 ; Cc1cccc(C)c1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3c1cc3c(cc1N2c1ccc2c(c1)C(C)(C)c1ccccc1C2(C)C)C(C)(C)c1ccccc1C3(C)C]

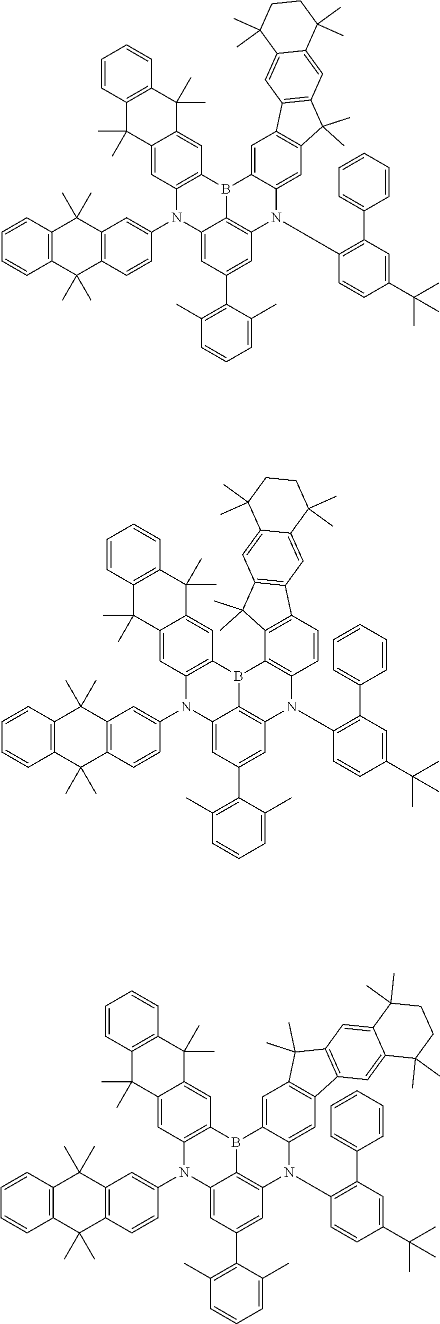

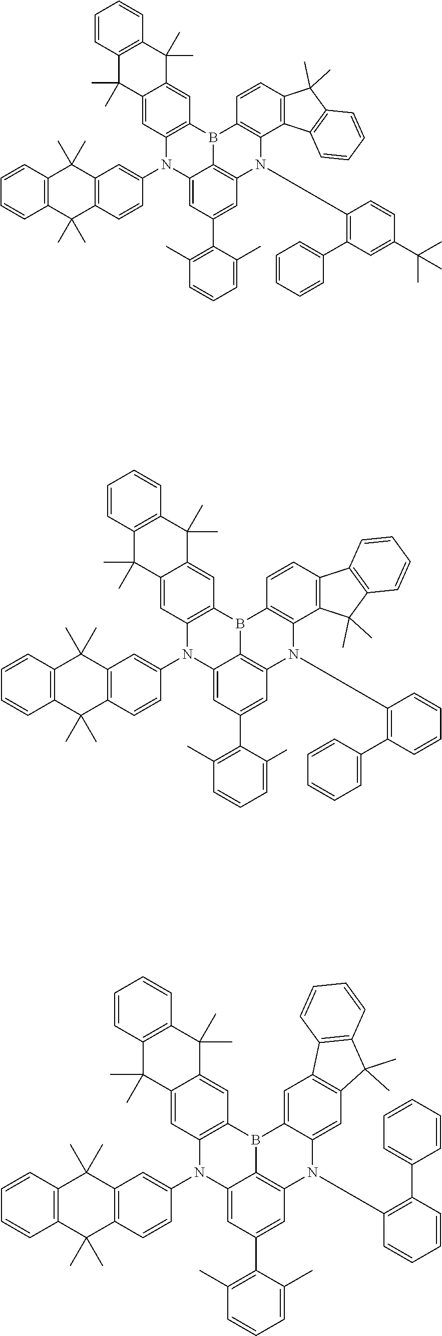 [SMILES: Cc1cccc(C)c1-c1cc2c3c(c1)N(c1ccc(C(C)(C)C)cc1-c1ccccc1)c1c(ccc4c1-c1ccccc1C4(C)C)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1c(ccc4c1C(C)(C)c1ccccc1-4)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)-c1ccccc1C4(C)C]

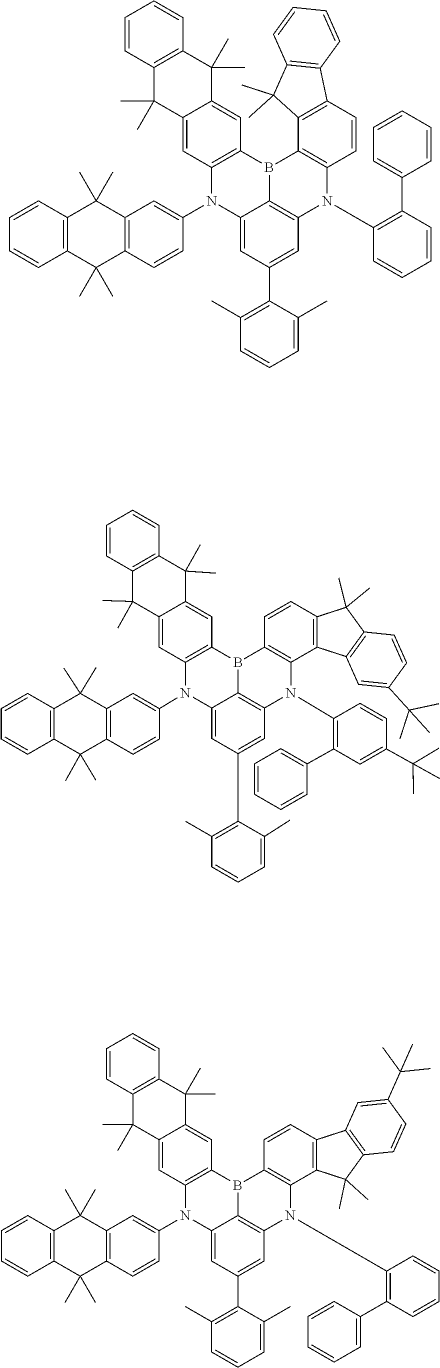 [SMILES: Cc1cccc(C)c1-c1cc2c3c(c1)N(c1ccccc1-c1ccccc1)c1ccc4c(c1B3c1cc3c(cc1N2c1ccc2c(c1)C(C)(C)c1ccccc1C2(C)C)C(C)(C)c1ccccc1C3(C)C)C(C)(C)c1ccccc1-4 ; Cc1cccc(C)c1-c1cc2c3c(c1)N(c1ccc(C(C)(C)C)cc1-c1ccccc1)c1c(ccc4c1-c1cc(C(C)(C)C)ccc1C4(C)C)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1c(ccc4c1C(C)(C)c1ccc(C(C)(C)C)cc1-4)B3c1cc3c(cc1N2c1ccc2c(c1)C(C)(C)c1ccccc1C2(C)C)C(C)(C)c1ccccc1C3(C)C]

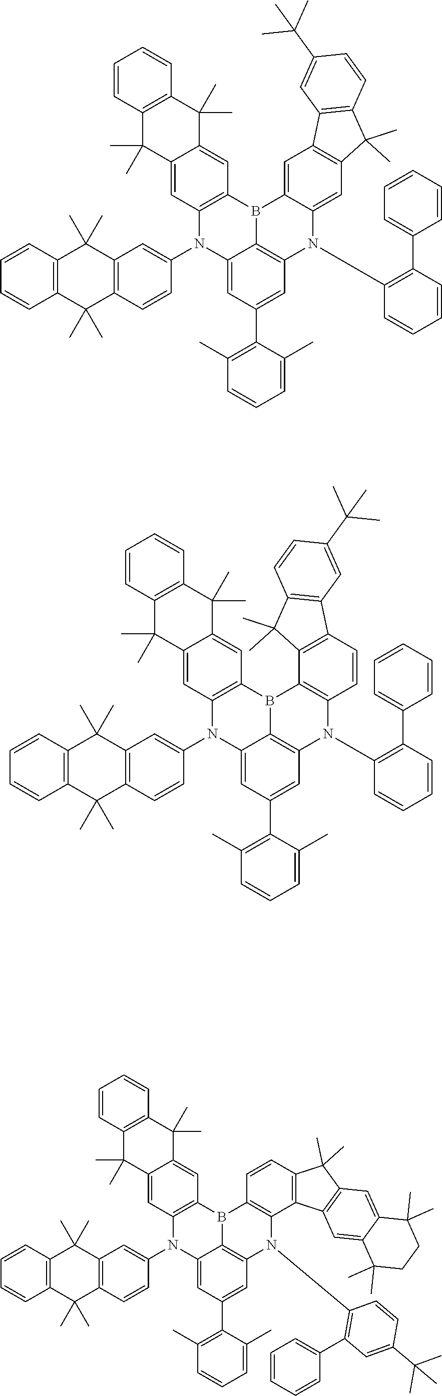 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)-c1cc(C(C)(C)C)ccc1C4(C)C ; Cc1cccc(C)c1-c1cc2c3c(c1)N(c1ccccc1-c1ccccc1)c1ccc4c(c1B3c1cc3c(cc1N2c1ccc2c(c1)C(C)(C)c1ccccc1C2(C)C)C(C)(C)c1ccccc1C3(C)C)C(C)(C)c1ccc(C(C)(C)C)cc1-4 ; Cc1cccc(C)c1-c1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1ccc2c(c1)C(C)(C)c1ccccc1C2(C)C)C(C)(C)c1ccccc1C3(C)C]

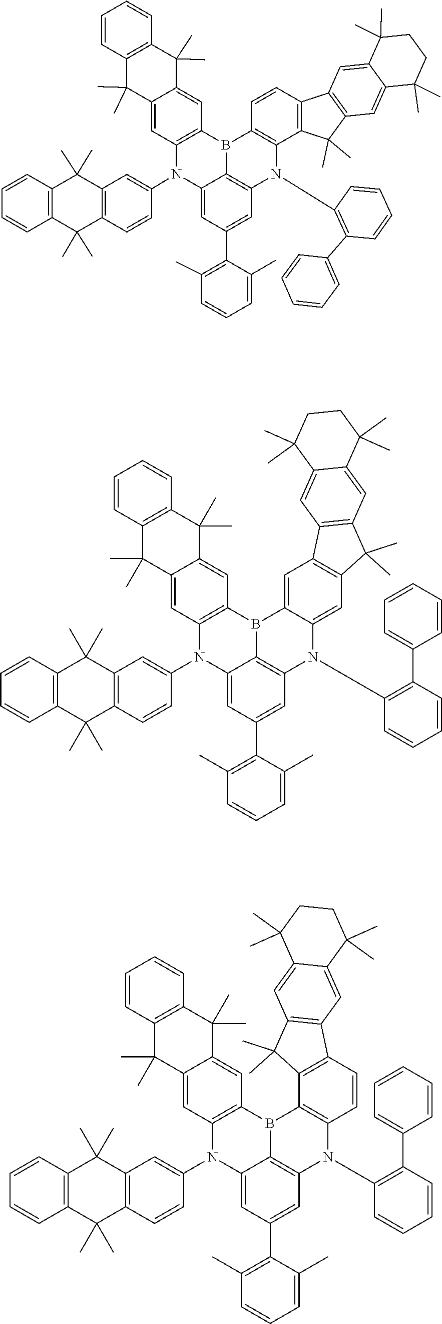 [SMILES: Cc1cccc(C)c1-c1cc2c3c(c1)N(c1ccccc1-c1ccccc1)c1c(ccc4c1C(C)(C)c1cc5c(cc1-4)C(C)(C)CCC5(C)C)B3c1cc3c(cc1N2c1ccc2c(c1)C(C)(C)c1ccccc1C2(C)C)C(C)(C)c1ccccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)-c1cc2c(cc1C4(C)C)C(C)(C)CCC2(C)C ; Cc1cccc(C)c1-c1cc2c3c(c1)N(c1ccccc1-c1ccccc1)c1ccc4c(c1B3c1cc3c(cc1N2c1ccc2c(c1)C(C)(C)c1ccccc1C2(C)C)C(C)(C)c1ccccc1C3(C)C)C(C)(C)c1cc2c(cc1-4)C(C)(C)CCC2(C)C]

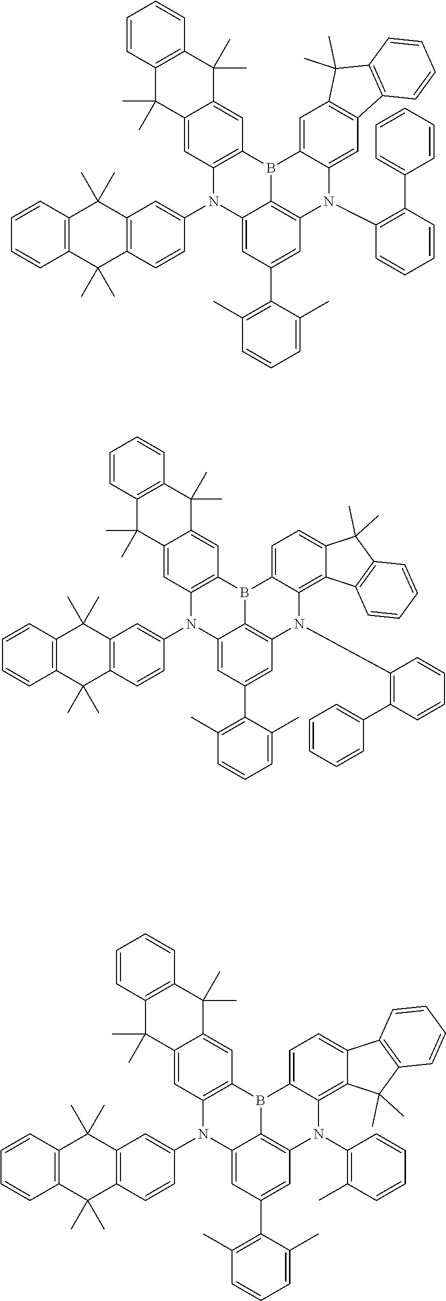 [SMILES: Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1-4 ; Cc1cccc(C)c1-c1cc2c3c(c1)N(c1ccccc1-c1ccccc1)c1c(ccc4c1-c1ccccc1C4(C)C)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)C(C)(C)c1ccccc1-3]

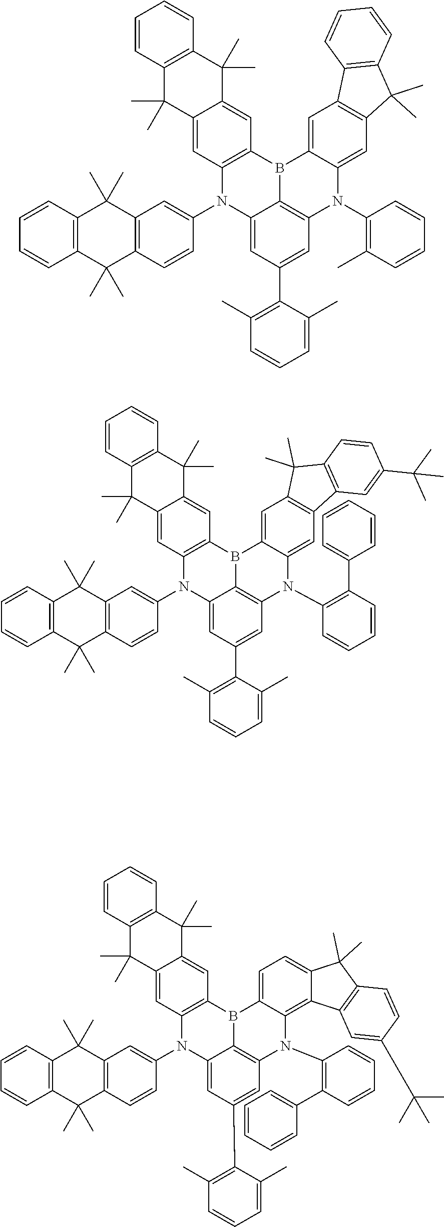 [SMILES: Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)-c1ccccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1ccc(C(C)(C)C)cc1-4 ; Cc1cccc(C)c1-c1cc2c3c(c1)N(c1ccccc1-c1ccccc1)c1c(ccc4c1-c1cc(C(C)(C)C)ccc1C4(C)C)B3c1cc3c(cc1N2c1ccc2c(c1)C(C)(C)c1ccccc1C2(C)C)C(C)(C)c1ccccc1C3(C)C]

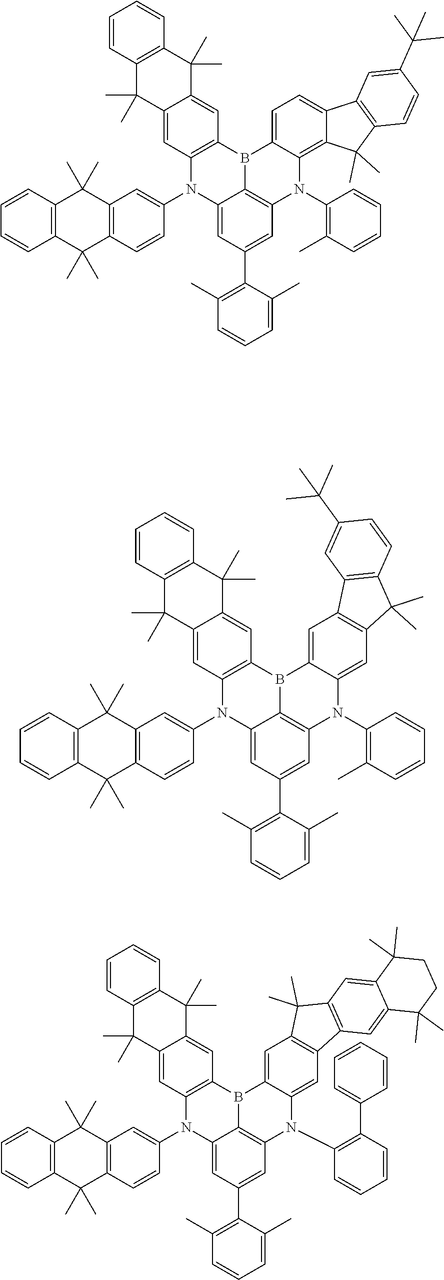 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)C(C)(C)c1ccc(C(C)(C)C)cc1-3 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)-c1cc(C(C)(C)C)ccc1C3(C)C ; Cc1cccc(C)c1-c1cc2c3c(c1)N(c1ccccc1-c1ccccc1)c1cc4c(cc1B3c1cc3c(cc1N2c1ccc2c(c1)C(C)(C)c1ccccc1C2(C)C)C(C)(C)c1ccccc1C3(C)C)C(C)(C)c1cc2c(cc1-4)C(C)(C)CCC2(C)C]

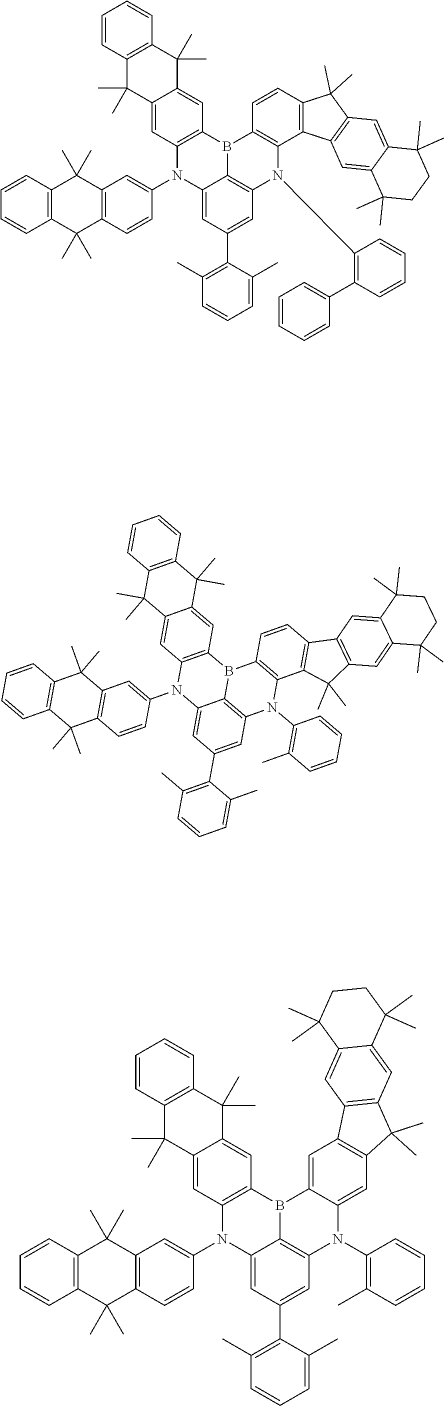 [SMILES: Cc1cccc(C)c1-c1cc2c3c(c1)N(c1ccccc1-c1ccccc1)c1c(ccc4c1-c1cc5c(cc1C4(C)C)C(C)(C)CCC5(C)C)B3c1cc3c(cc1N2c1ccc2c(c1)C(C)(C)c1ccccc1C2(C)C)C(C)(C)c1ccccc1C3(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)C(C)(C)c1cc2c(cc1-3)C(C)(C)CCC2(C)C ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)-c1cc2c(cc1C3(C)C)C(C)(C)CCC2(C)C]

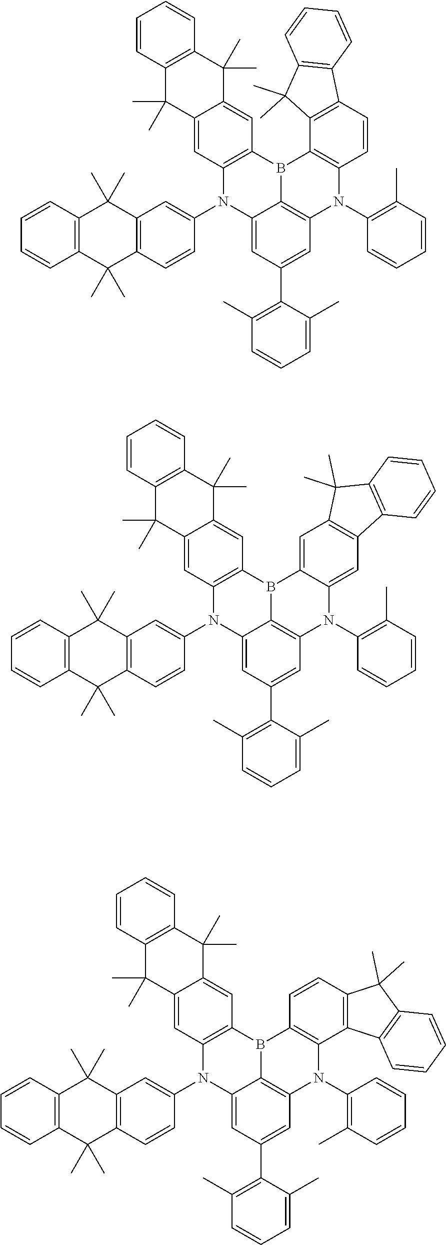 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccccc2-1 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)C(C)(C)c1ccccc1-3 ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)-c1ccccc1C3(C)C]

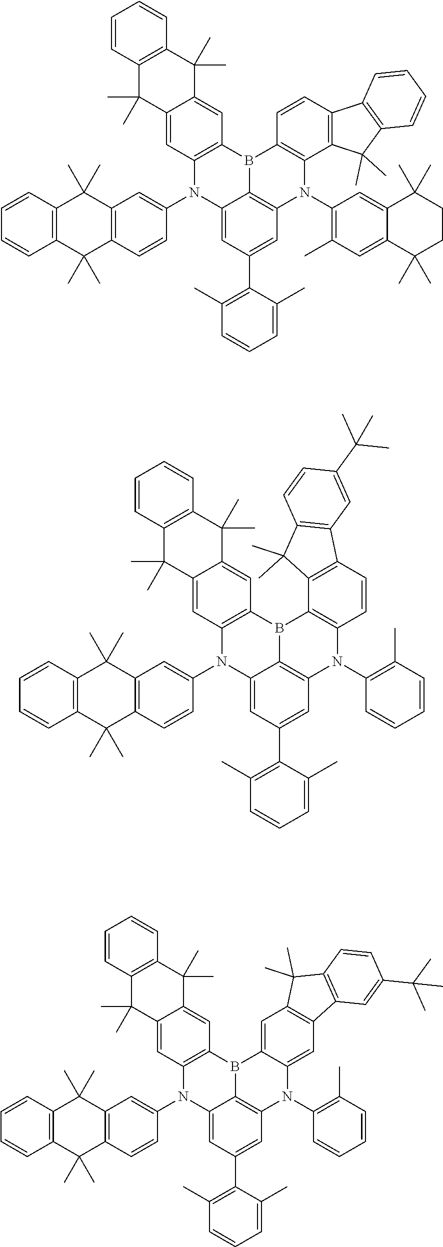 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1ccccc1-4)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2ccc(C(C)(C)C)cc2-1 ; Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)C(C)(C)c1ccc(C(C)(C)C)cc1-3]

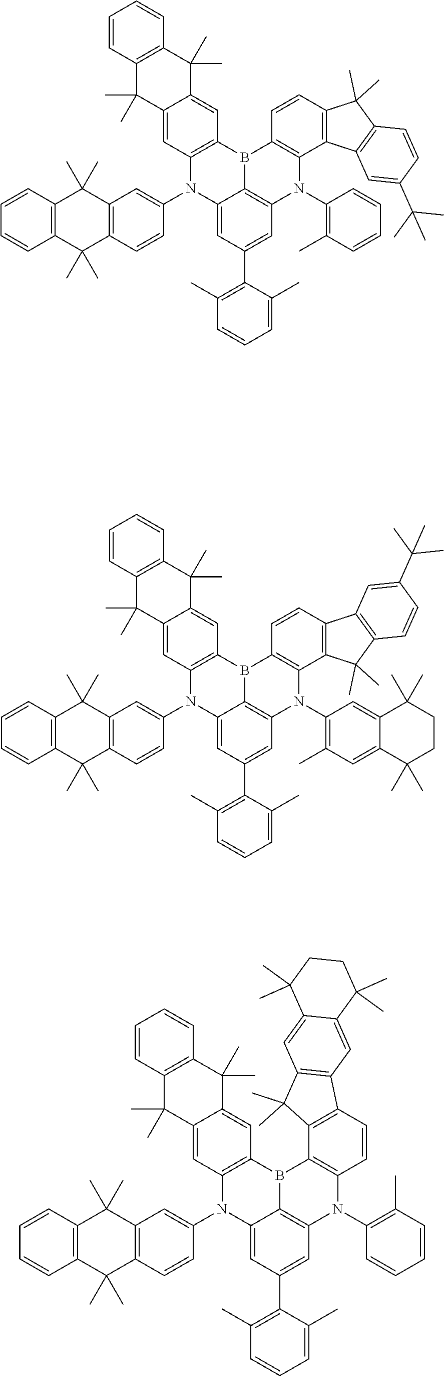 [SMILES: Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)-c1cc(C(C)(C)C)ccc1C3(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1ccc(C(C)(C)C)cc1-4)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2c1ccc1c2C(C)(C)c2cc3c(cc2-1)C(C)(C)CCC3(C)C]

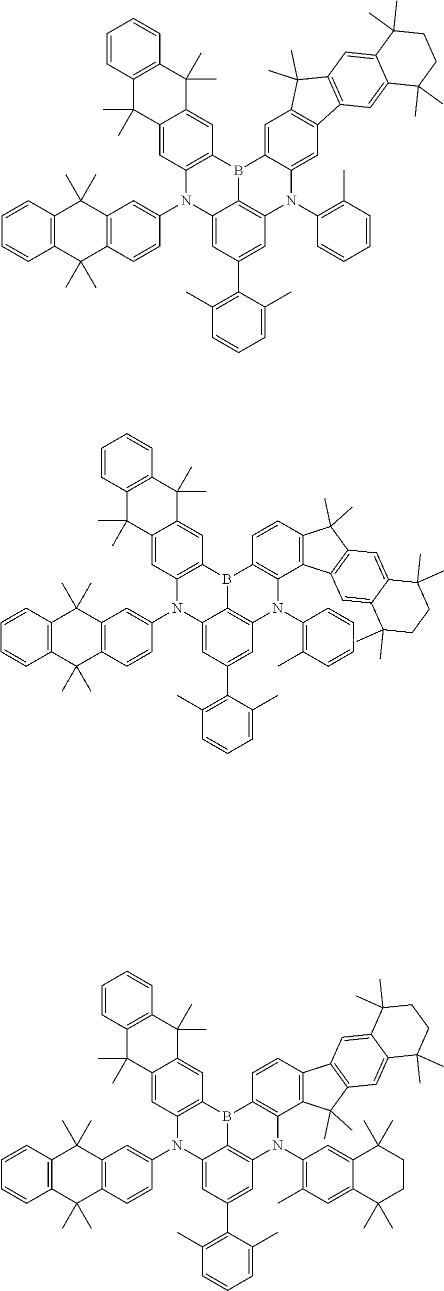 [SMILES: Cc1ccccc1N1c2cc3c(cc2B2c4cc5c(cc4N(c4ccc6c(c4)C(C)(C)c4ccccc4C6(C)C)c4cc(-c6c(C)cccc6C)cc1c42)C(C)(C)c1ccccc1C5(C)C)C(C)(C)c1cc2c(cc1-3)C(C)(C)CCC2(C)C ; Cc1ccccc1N1c2cc(-c3c(C)cccc3C)cc3c2B(c2cc4c(cc2N3c2ccc3c(c2)C(C)(C)c2ccccc2C3(C)C)C(C)(C)c2ccccc2C4(C)C)c2ccc3c(c21)-c1cc2c(cc1C3(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)C(C)(C)c1cc3c(cc1-4)C(C)(C)CCC3(C)C)C(C)(C)CCC2(C)C]

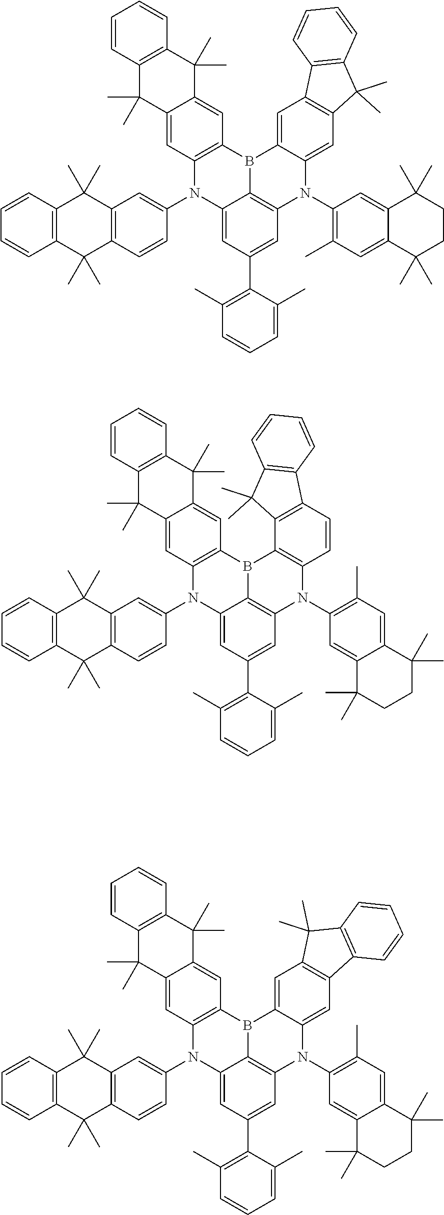 [SMILES: Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)-c1ccccc1C4(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3C(C)(C)c3ccccc3-1)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)C(C)(C)c1ccccc1-4)C(C)(C)CCC2(C)C]

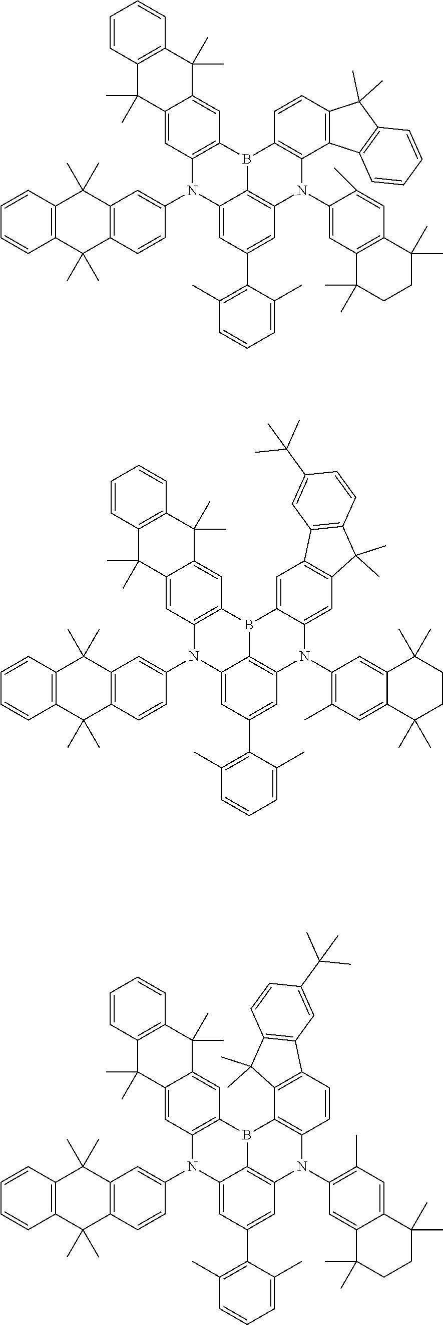 [SMILES: Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)-c1ccccc1C4(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)-c1cc(C(C)(C)C)ccc1C4(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3c1ccc1c3C(C)(C)c3ccc(C(C)(C)C)cc3-1)C(C)(C)CCC2(C)C]

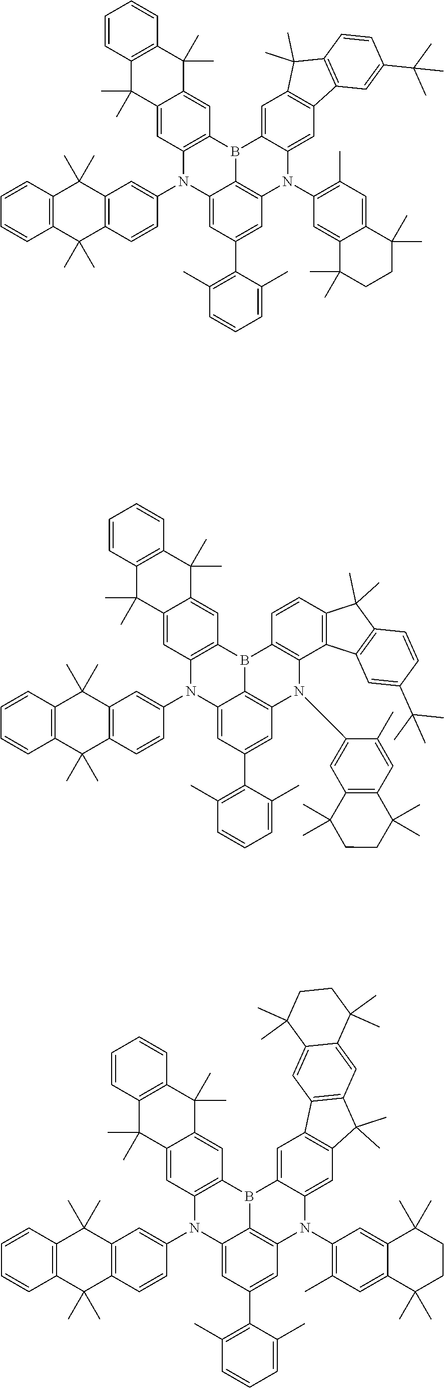 [SMILES: Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)C(C)(C)c1ccc(C(C)(C)C)cc1-4)C(C)(C)CCC2(C)C ; Cc1cc2c(cc1N1c3cc(-c4c(C)cccc4C)cc4c3B(c3cc5c(cc3N4c3ccc4c(c3)C(C)(C)c3ccccc3C4(C)C)C(C)(C)c3ccccc3C5(C)C)c3ccc4c(c31)-c1cc(C(C)(C)C)ccc1C4(C)C)C(C)(C)CCC2(C)C ; Cc1cc2c(cc1N1c3cc4c(cc3B3c5cc6c(cc5N(c5ccc7c(c5)C(C)(C)c5ccccc5C7(C)C)c5cc(-c7c(C)cccc7C)cc1c53)C(C)(C)c1ccccc1C6(C)C)-c1cc3c(cc1C4(C)C)C(C)(C)CCC3(C)C)C(C)(C)CCC2(C)C]

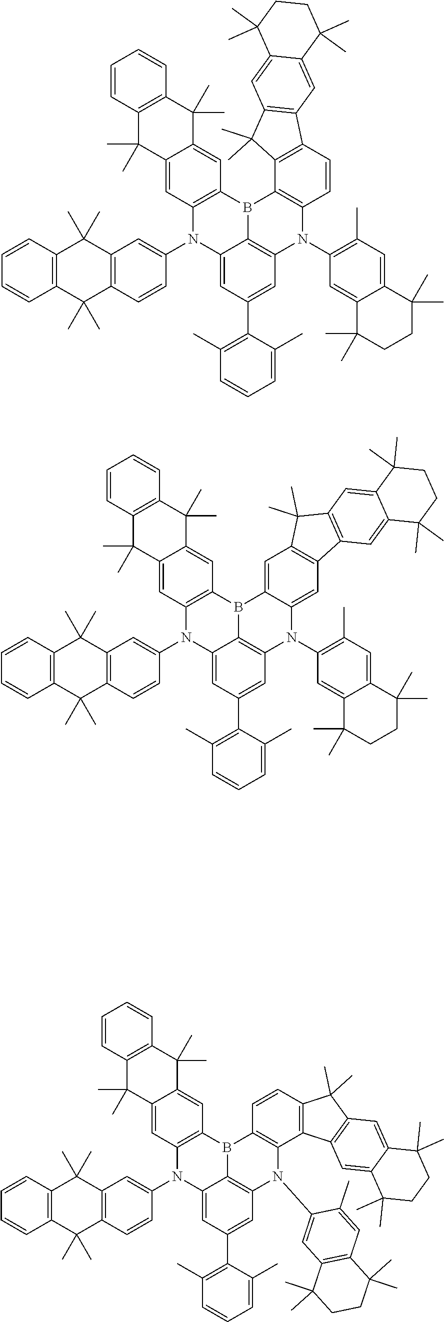

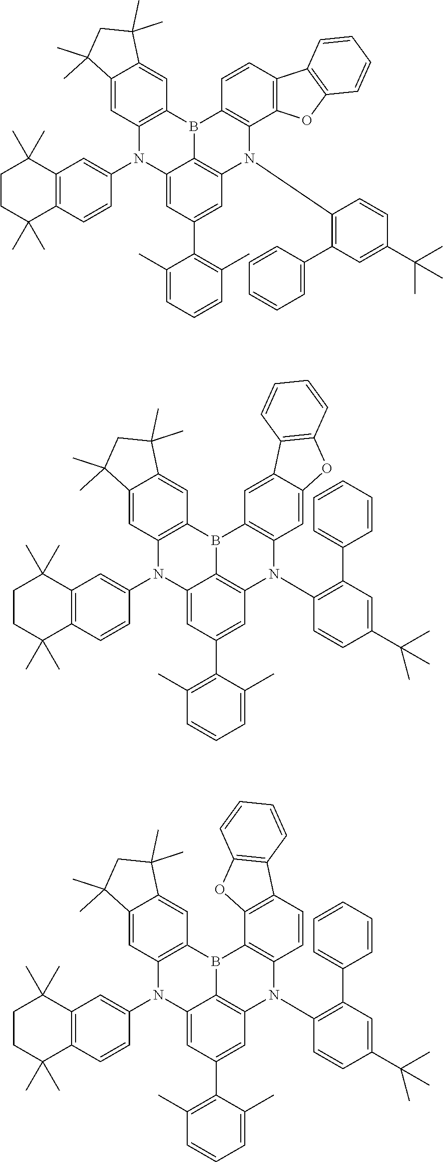 [SMILES: Cc1cccc(C)c1-c1cc2c3c(c1)N(c1ccc(C(C)(C)C)cc1-c1ccccc1)c1c(ccc4c1oc1ccccc14)B3c1cc3c(cc1N2c1ccc2c(c1)C(C)(C)CCC2(C)C)C(C)(C)CC3(C)C ; Cc1cccc(C)c1-c1cc2c3c(c1)N(c1ccc(C(C)(C)C)cc1-c1ccccc1)c1cc4oc5ccccc5c4cc1B3c1cc3c(cc1N2c1ccc2c(c1)C(C)(C)CCC2(C)C)C(C)(C)CC3(C)C ; Cc1cccc(C)c1-c1cc2c3c(c1)N(c1ccc(C(C)(C)C)cc1-c1ccccc1)c1ccc4c(oc5ccccc54)c1B3c1cc3c(cc1N2c1ccc2c(c1)C(C)(C)CCC2(C)C)C(C)(C)CC3(C)C]

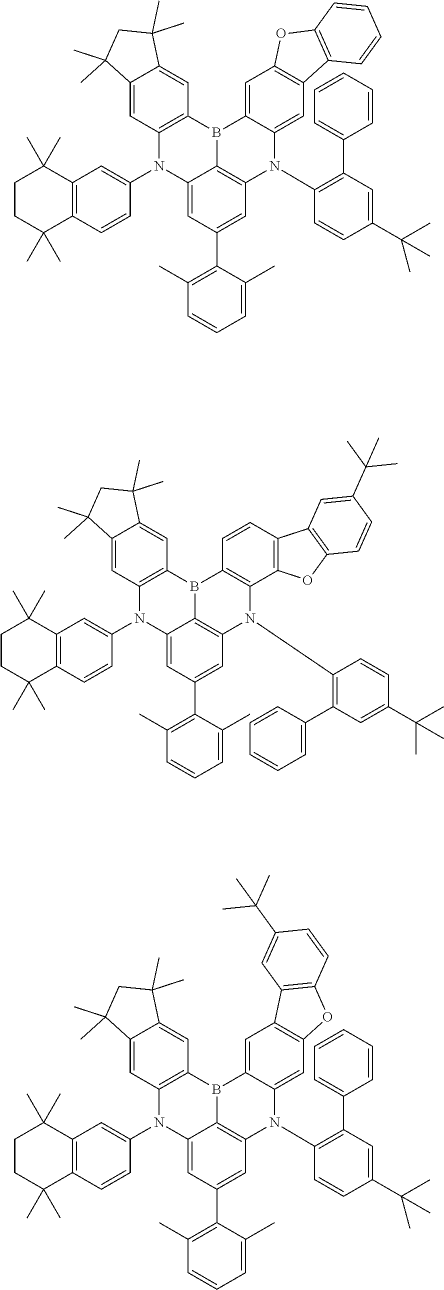 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CC3(C)C)oc1ccccc14 ; Cc1cccc(C)c1-c1cc2c3c(c1)N(c1ccc(C(C)(C)C)cc1-c1ccccc1)c1c(ccc4c1oc1ccc(C(C)(C)C)cc14)B3c1cc3c(cc1N2c1ccc2c(c1)C(C)(C)CCC2(C)C)C(C)(C)CC3(C)C ; Cc1cccc(C)c1-c1cc2c3c(c1)N(c1ccc(C(C)(C)C)cc1-c1ccccc1)c1cc4oc5ccc(C(C)(C)C)cc5c4cc1B3c1cc3c(cc1N2c1ccc2c(c1)C(C)(C)CCC2(C)C)C(C)(C)CC3(C)C]

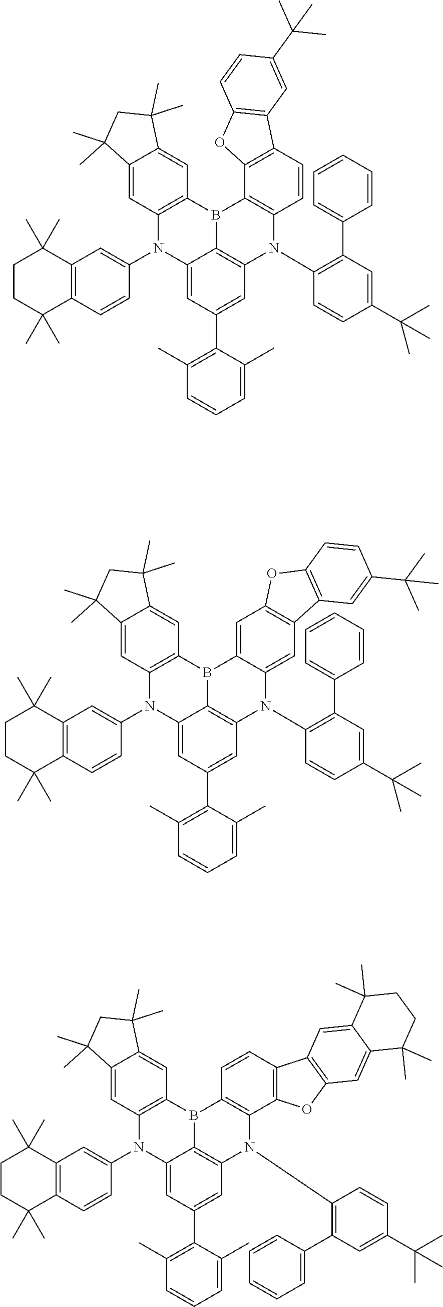 [SMILES: Cc1cccc(C)c1-c1cc2c3c(c1)N(c1ccc(C(C)(C)C)cc1-c1ccccc1)c1ccc4c(oc5ccc(C(C)(C)C)cc54)c1B3c1cc3c(cc1N2c1ccc2c(c1)C(C)(C)CCC2(C)C)C(C)(C)CC3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CC3(C)C)oc1ccc(C(C)(C)C)cc14 ; Cc1cccc(C)c1-c1cc2c3c(c1)N(c1ccc(C(C)(C)C)cc1-c1ccccc1)c1c(ccc4c1oc1cc5c(cc14)C(C)(C)CCC5(C)C)B3c1cc3c(cc1N2c1ccc2c(c1)C(C)(C)CCC2(C)C)C(C)(C)CC3(C)C]

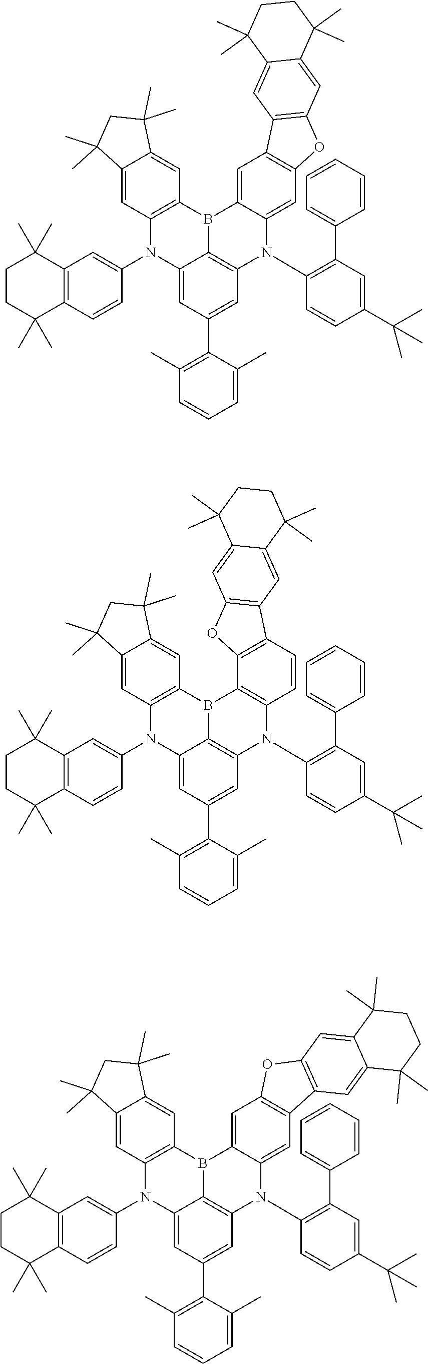 [SMILES: Cc1cccc(C)c1-c1cc2c3c(c1)N(c1ccc(C(C)(C)C)cc1-c1ccccc1)c1cc4oc5cc6c(cc5c4cc1B3c1cc3c(cc1N2c1ccc2c(c1)C(C)(C)CCC2(C)C)C(C)(C)CC3(C)C)C(C)(C)CCC6(C)C ; Cc1cccc(C)c1-c1cc2c3c(c1)N(c1ccc(C(C)(C)C)cc1-c1ccccc1)c1ccc4c(oc5cc6c(cc54)C(C)(C)CCC6(C)C)c1B3c1cc3c(cc1N2c1ccc2c(c1)C(C)(C)CCC2(C)C)C(C)(C)CC3(C)C ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CC3(C)C)oc1cc2c(cc14)C(C)(C)CCC2(C)C]

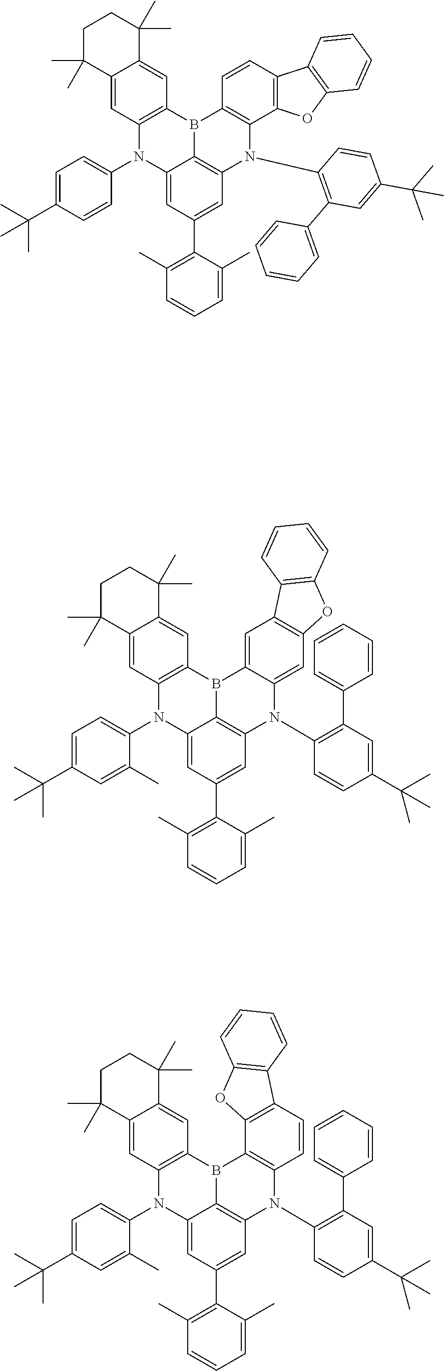

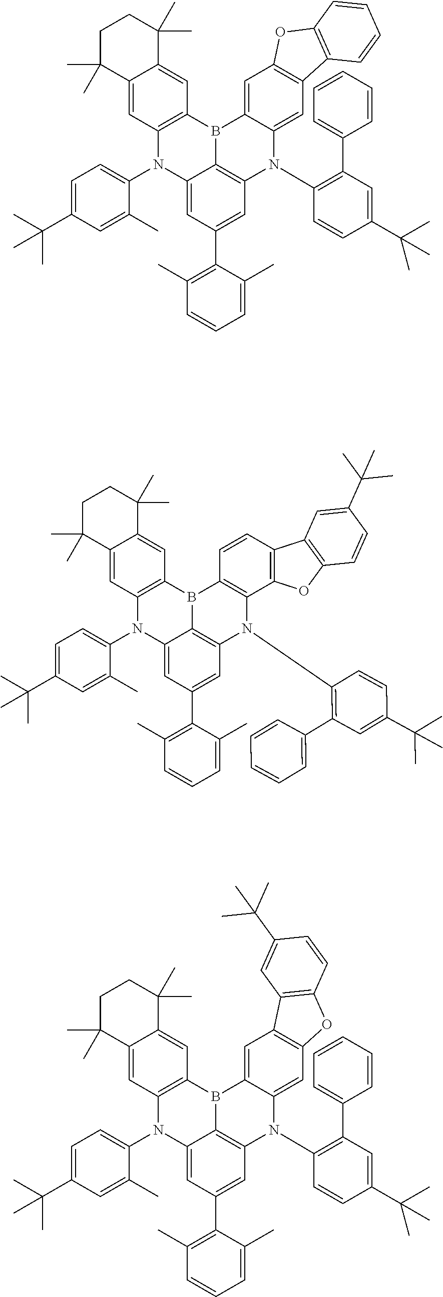

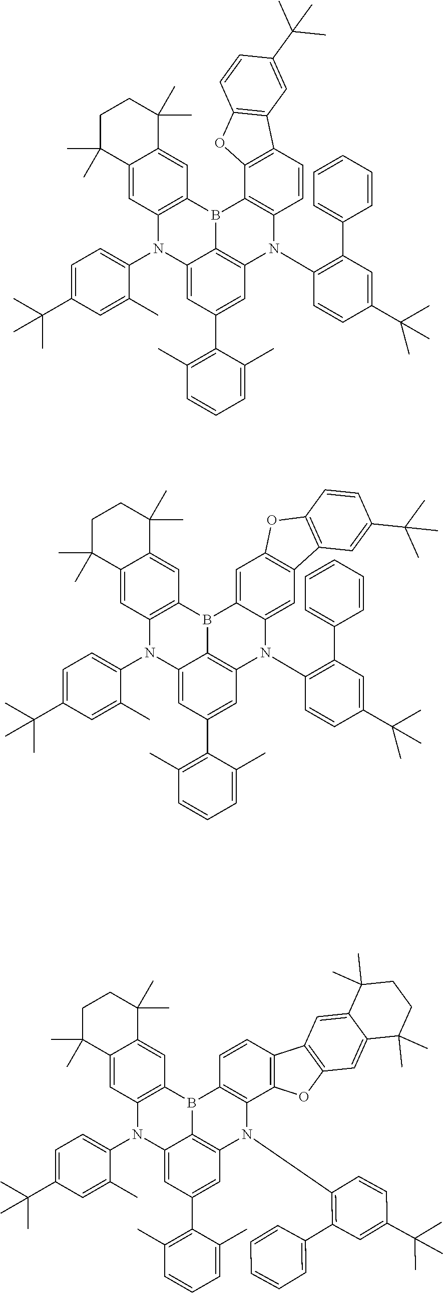

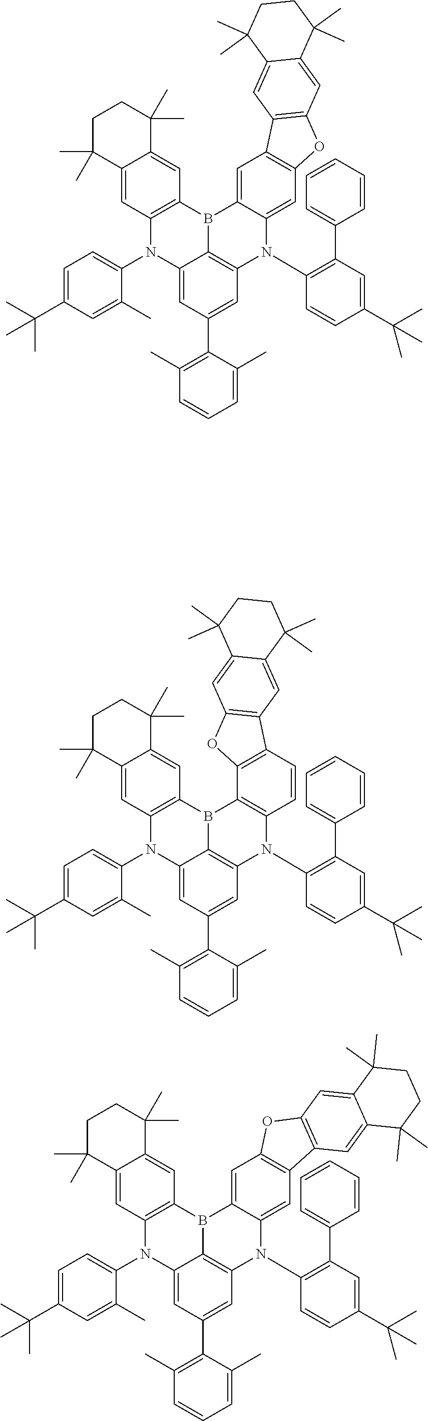

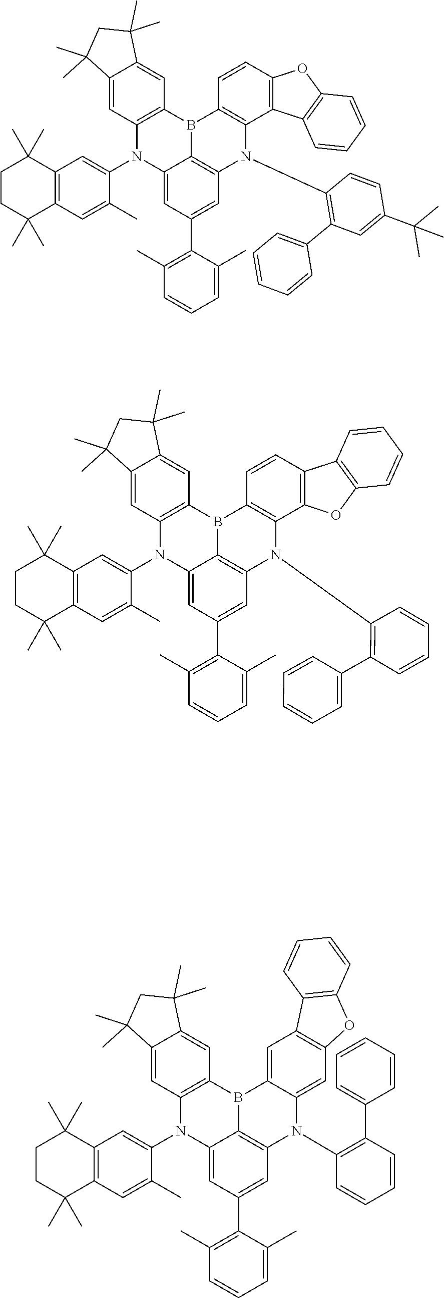 [SMILES: Cc1cc2c(cc1N1c3cc4c(cc3B3c5ccc6oc7ccccc7c6c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)oc1ccccc16)C(C)(C)CC4(C)C)C(C)(C)CCC2(C)C]

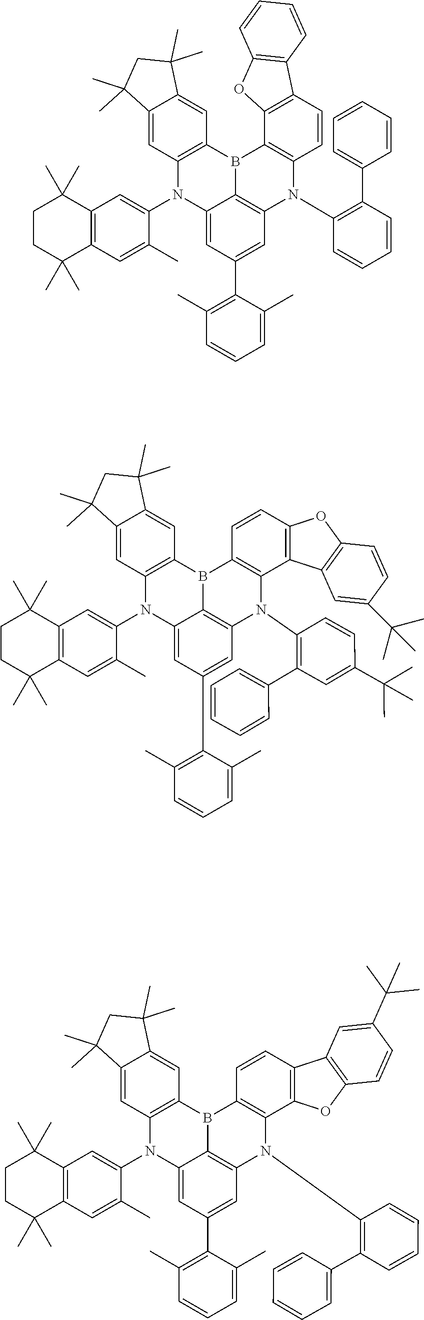 [SMILES: Cc1cc2c(cc1N1c3cc4c(cc3B3c5c1cc(-c1c(C)cccc1C)cc5N(c1ccccc1-c1ccccc1)c1ccc5c(oc6ccccc65)c13)C(C)(C)CC4(C)C)C(C)(C)CCC2(C)C ; Cc1cc2c(cc1N1c3cc4c(cc3B3c5ccc6oc7ccc(C(C)(C)C)cc7c6c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5ccccc5-c5ccccc5)c5cc(-c6c(C)cccc6C)cc1c53)C(C)(C)CC4(C)C)C(C)(C)CCC2(C)C]

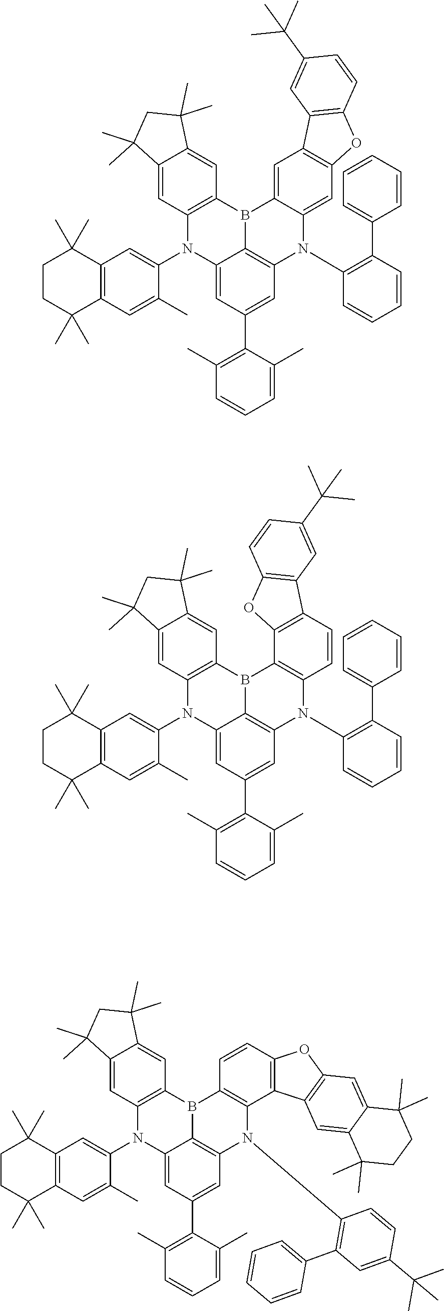 [SMILES: Cc1cc2c(cc1N1c3cc4c(cc3B3c5cc6c(cc5N(c5ccccc5-c5ccccc5)c5cc(-c7c(C)cccc7C)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(oc6ccc(C(C)(C)C)cc65)c13)C(C)(C)CC4(C)C)C(C)(C)CCC2(C)C ; Cc1cc2c(cc1N1c3cc4c(cc3B3c5ccc6oc7cc8c(cc7c6c5N(c5ccc(C(C)(C)C)cc5-c5ccccc5)c5cc(-c6c(C)cccc6C)cc1c53)C(C)(C)CCC8(C)C)C(C)(C)CC4(C)C)C(C)(C)CCC2(C)C]

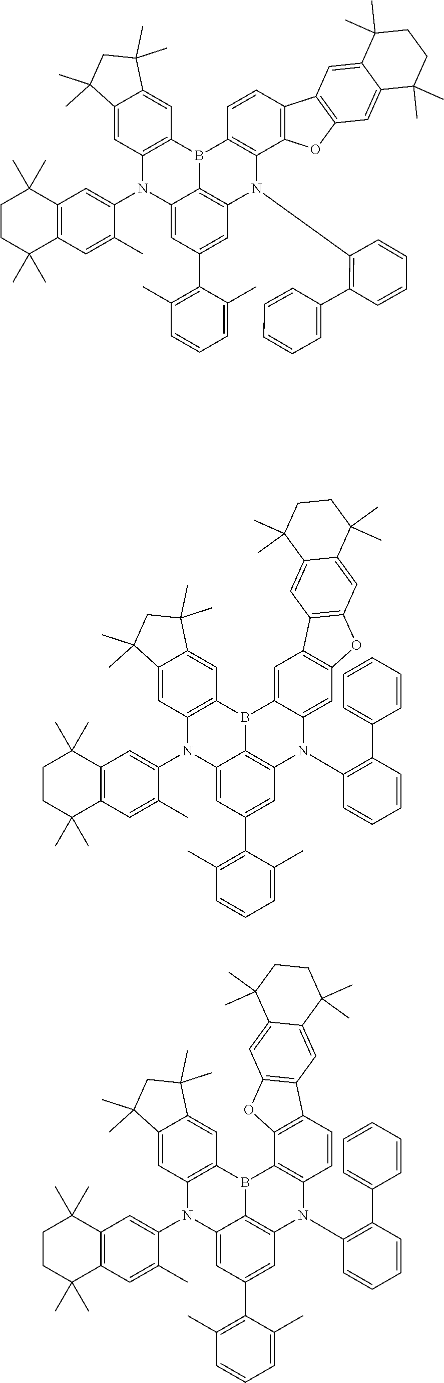 [SMILES: Cc1cc2c(cc1N1c3cc4c(cc3B3c5ccc6c(oc7cc8c(cc76)C(C)(C)CCC8(C)C)c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)oc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(oc6cc7c(cc65)C(C)(C)CCC7(C)C)c13)C(C)(C)CC4(C)C)C(C)(C)CCC2(C)C]

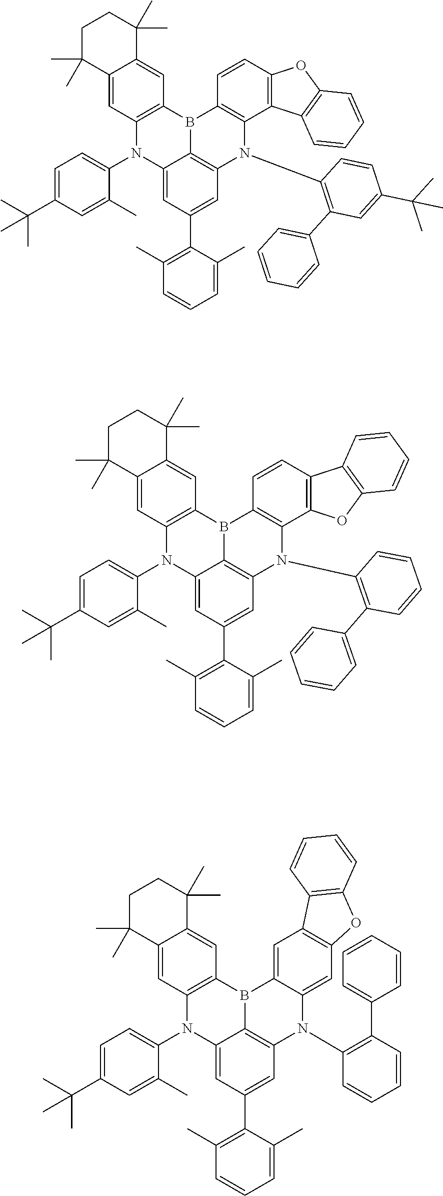

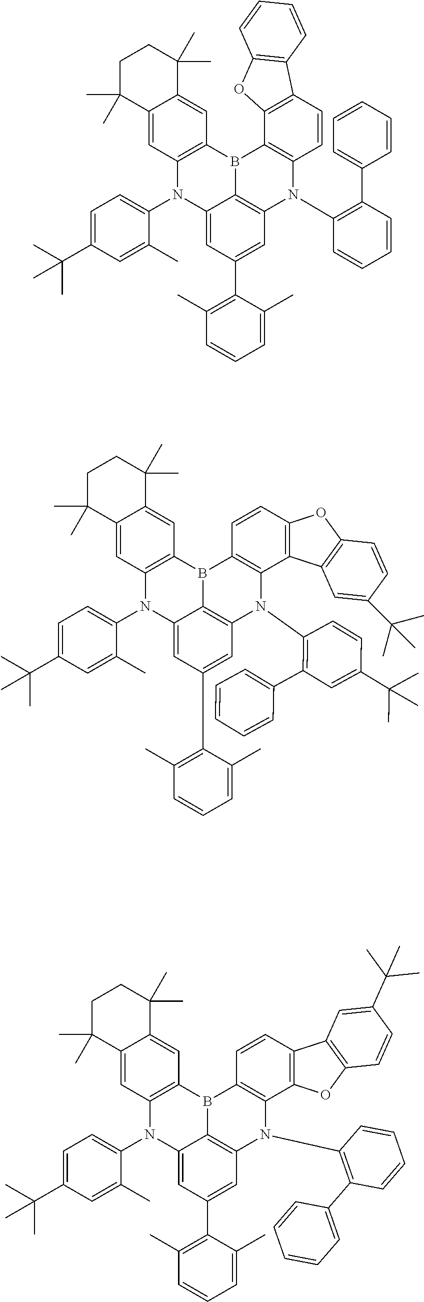

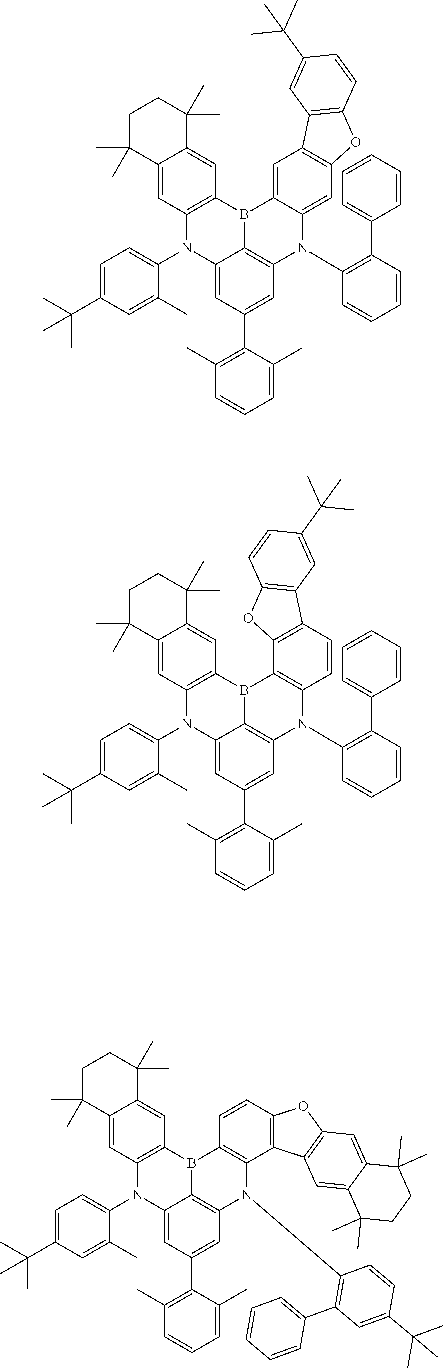 [SMILES: Cc1cc(C(C)(C)C)ccc1N1c2cc3c(cc2B2c4cc5c(cc4N(c4ccccc4-c4ccccc4)c4cc(-c6c(C)cccc6C)cc1c42)oc1ccc(C(C)(C)C)cc15)C(C)(C)CCC3(C)C ; Cc1cc(C(C)(C)C)ccc1N1c2cc3c(cc2B2c4c1cc(-c1c(C)cccc1C)cc4N(c1ccccc1-c1ccccc1)c1ccc4c(oc5ccc(C(C)(C)C)cc54)c12)C(C)(C)CCC3(C)C ; Cc1cc(C(C)(C)C)ccc1N1c2cc3c(cc2B2c4ccc5oc6cc7c(cc6c5c4N(c4ccc(C(C)(C)C)cc4-c4ccccc4)c4cc(-c5c(C)cccc5C)cc1c42)C(C)(C)CCC7(C)C)C(C)(C)CCC3(C)C]

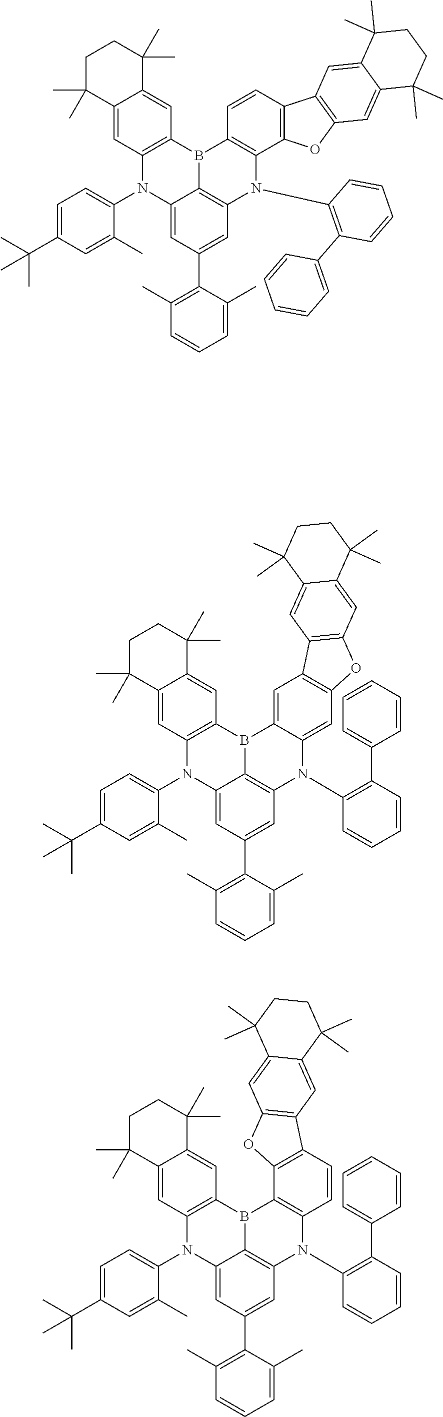

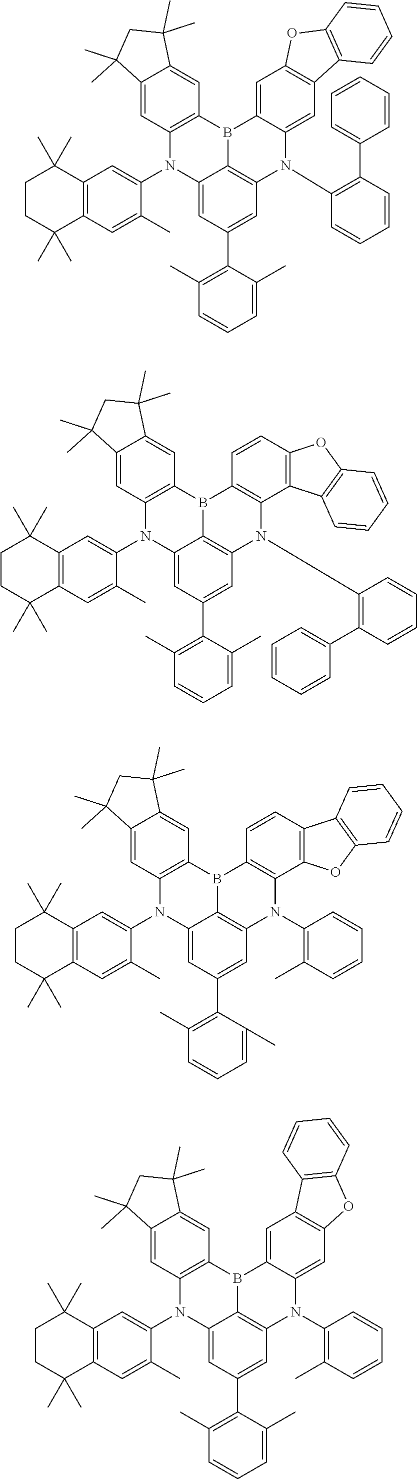 [SMILES: Cc1cc2c(cc1N1c3cc4c(cc3B3c5cc6oc7ccccc7c6cc5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5C)c5cc(-c6c(C)cccc6C)cc1c53)C(C)(C)CC4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(-c5c(C)cccc5C)cc1c32)C(C)(C)CC4(C)C]

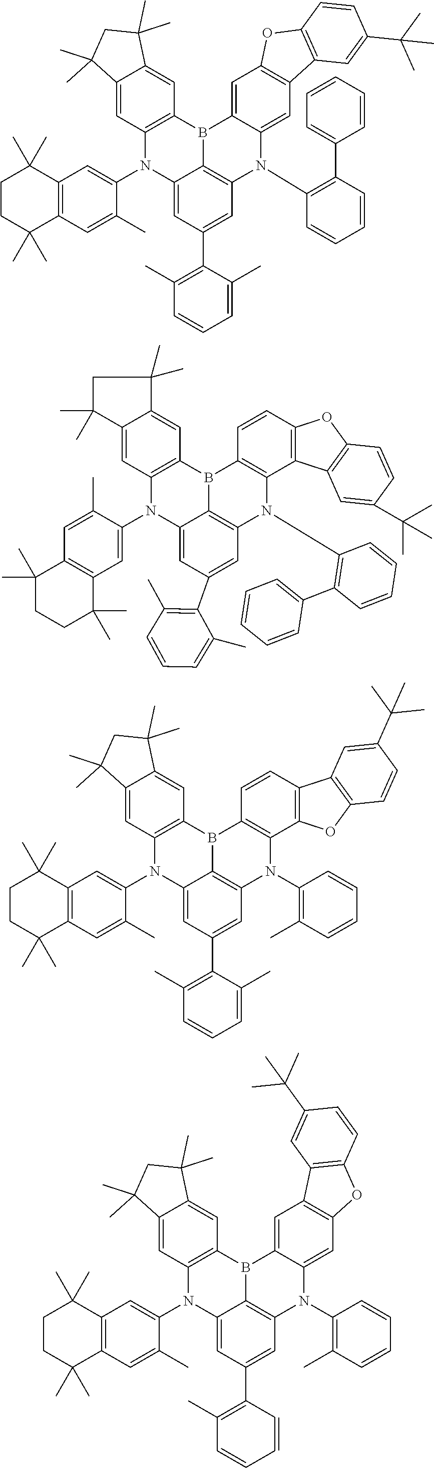

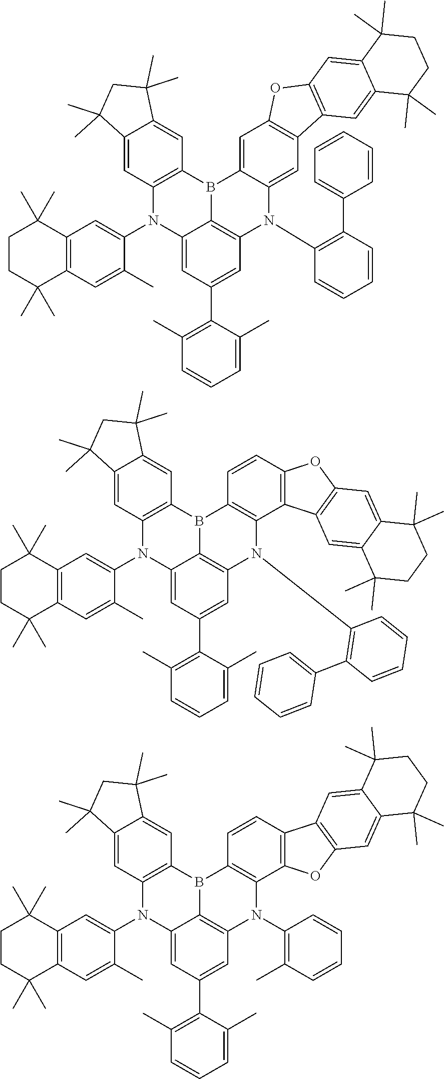

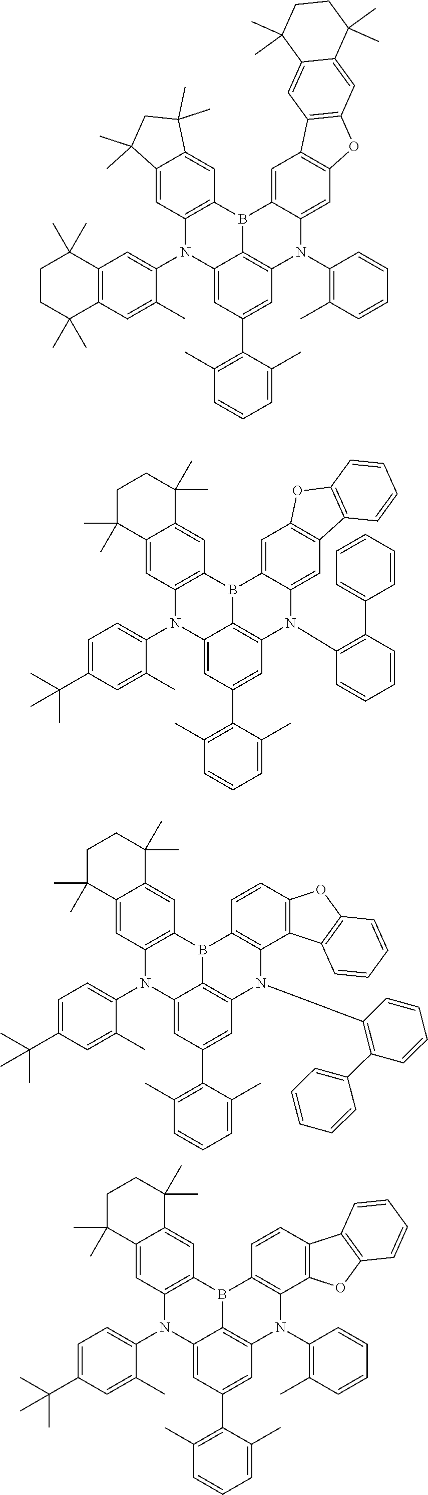

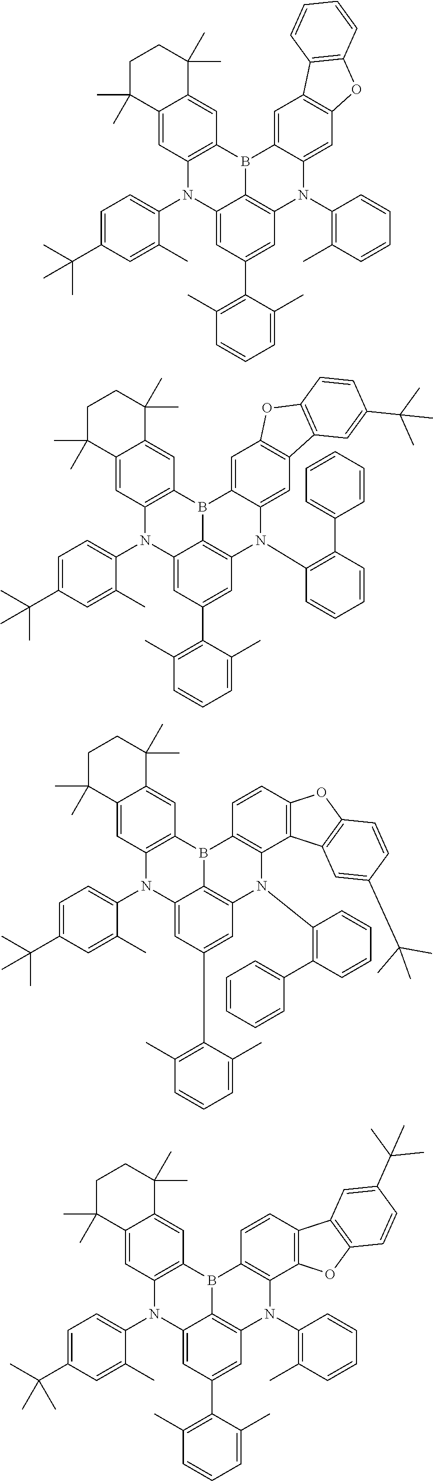

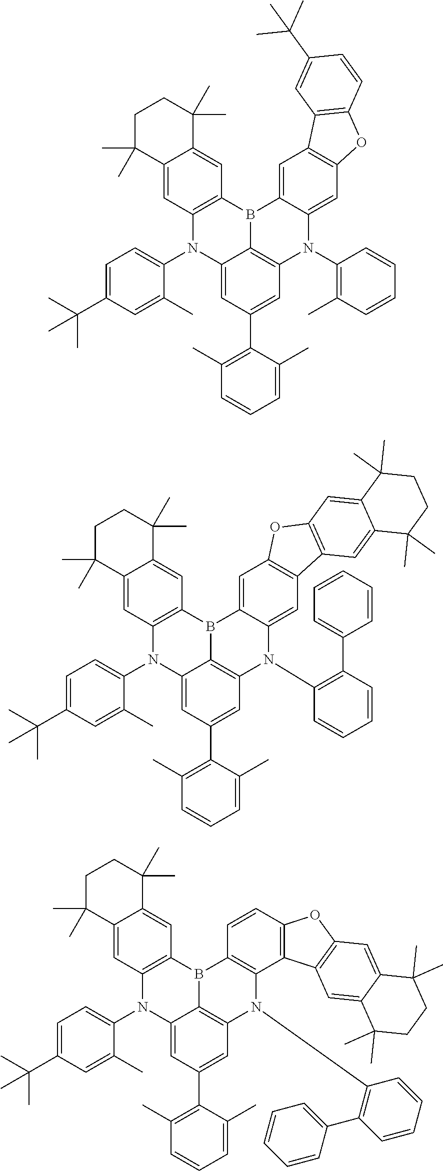

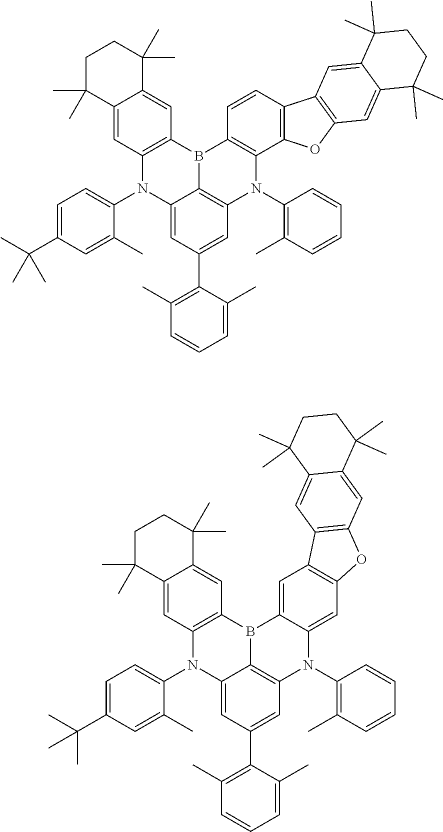

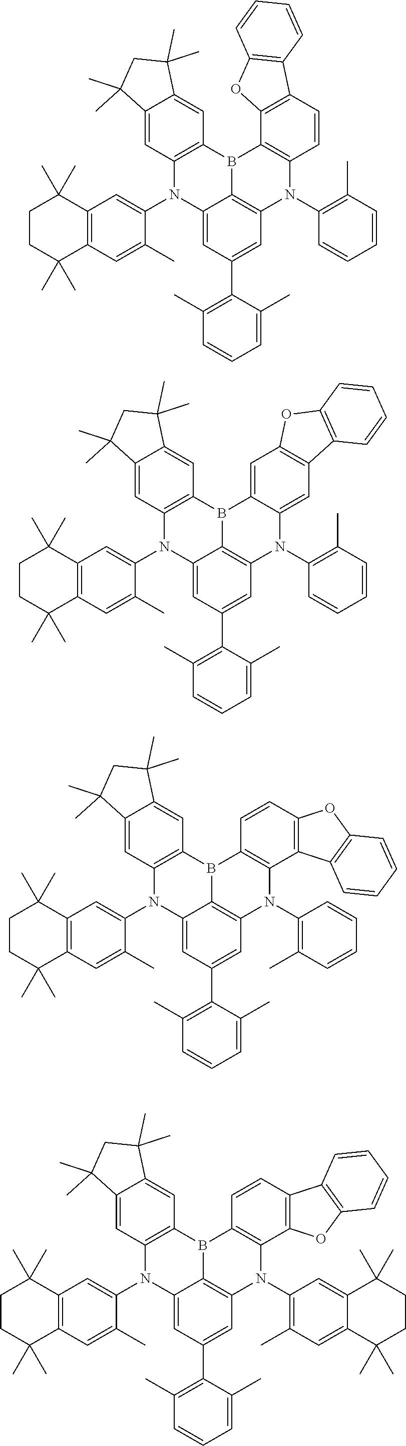 [SMILES: Cc1cc2c(cc1N1c3cc4c(cc3B3c5c1cc(-c1c(C)cccc1C)cc5N(c1ccccc1C)c1ccc5c(oc6ccccc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)oc1ccccc13 ; Cc1cc2c(cc1N1c3cc4c(cc3B3c5ccc6oc7ccccc7c6c5N(c5ccccc5C)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(-c6c(C)cccc6C)cc1c53)C(C)(C)CC4(C)C)C(C)(C)CCC2(C)C]

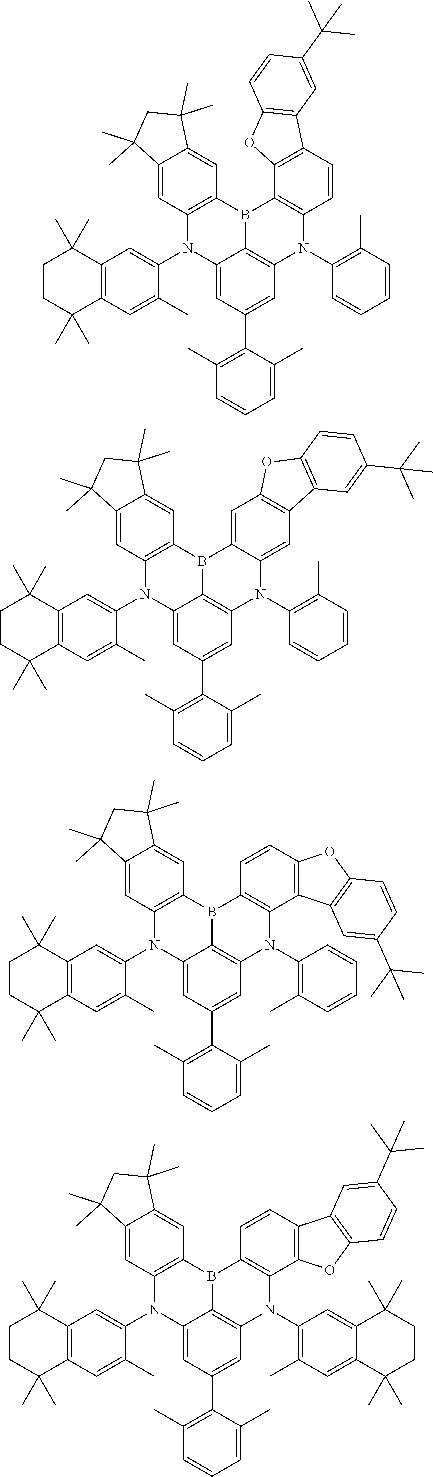

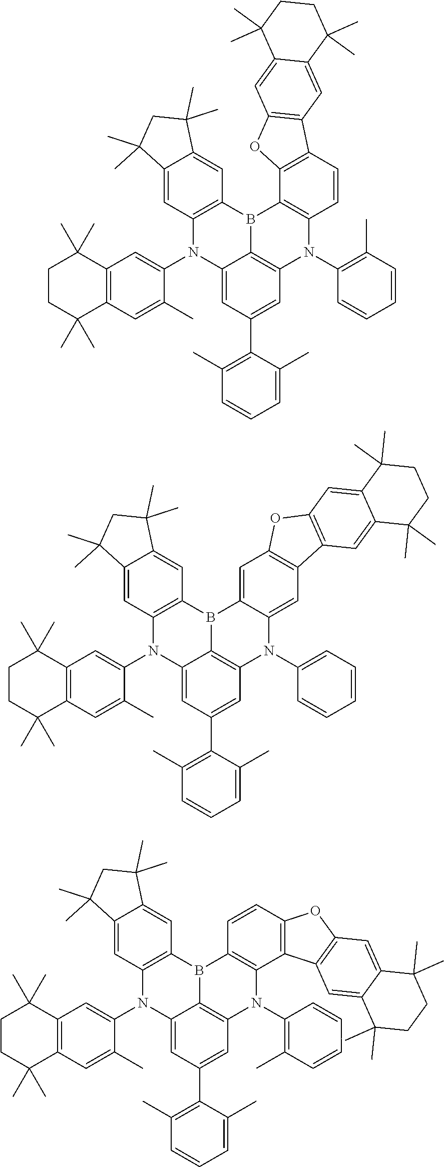 [SMILES: Cc1cc2c(cc1N1c3cc4c(cc3B3c5c1cc(-c1c(C)cccc1C)cc5N(c1ccccc1C)c1ccc5c(oc6cc7c(cc65)C(C)(C)CCC7(C)C)c13)C(C)(C)CC4(C)C)C(C)(C)CCC2(C)C ; Cc1cc2c(cc1N1c3cc4c(cc3B3c5cc6oc7cc8c(cc7c6cc5N(c5ccccc5)c5cc(-c6c(C)cccc6C)cc1c53)C(C)(C)CCC8(C)C)C(C)(C)CC4(C)C)C(C)(C)CCC2(C)C ; Cc1cc2c(cc1N1c3cc4c(cc3B3c5ccc6oc7cc8c(cc7c6c5N(c5ccccc5C)c5cc(-c6c(C)cccc6C)cc1c53)C(C)(C)CCC8(C)C)C(C)(C)CC4(C)C)C(C)(C)CCC2(C)C]

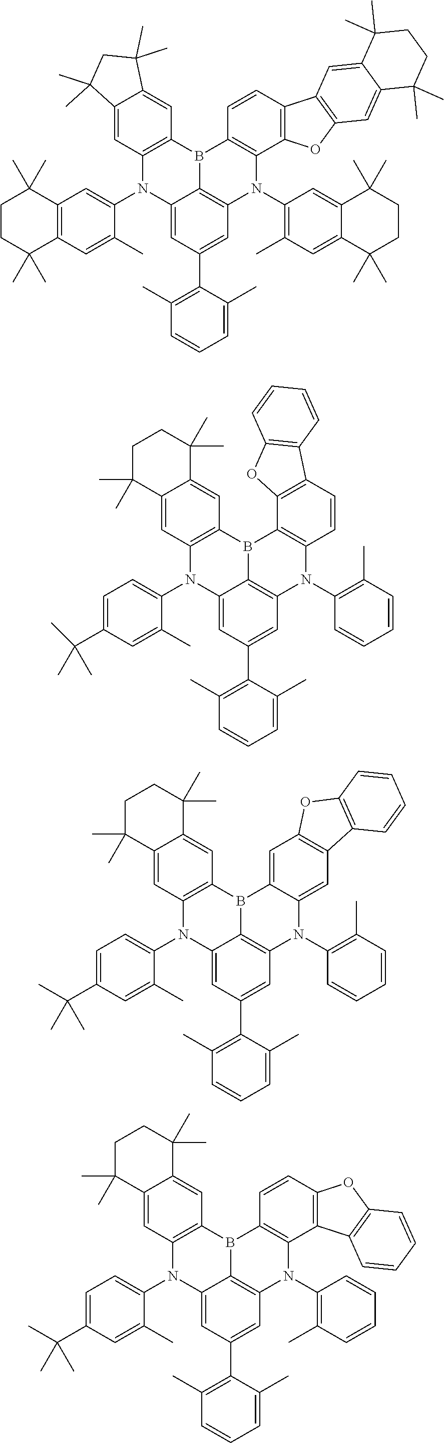

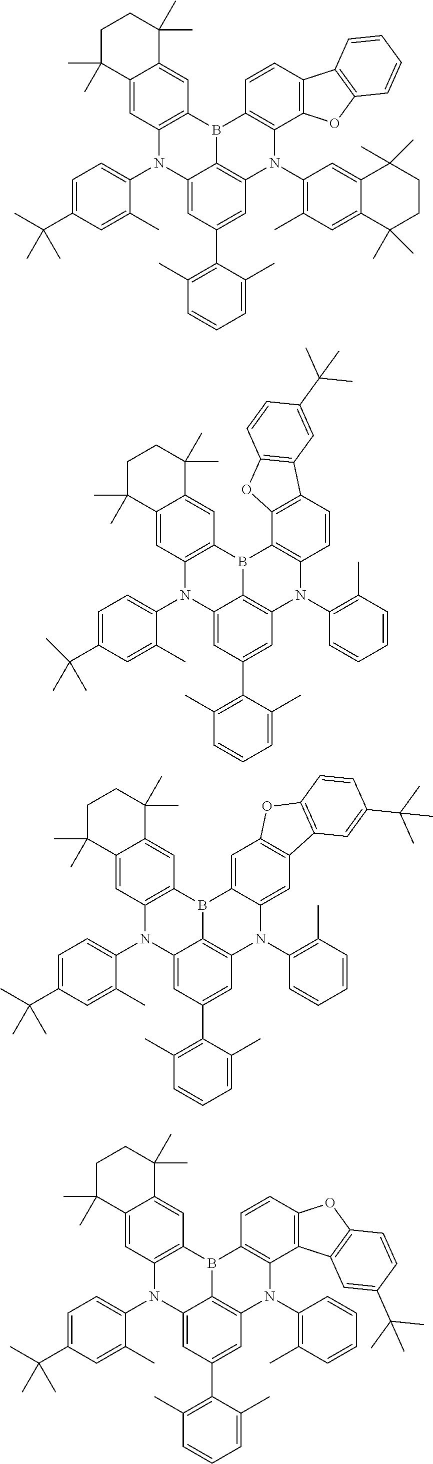

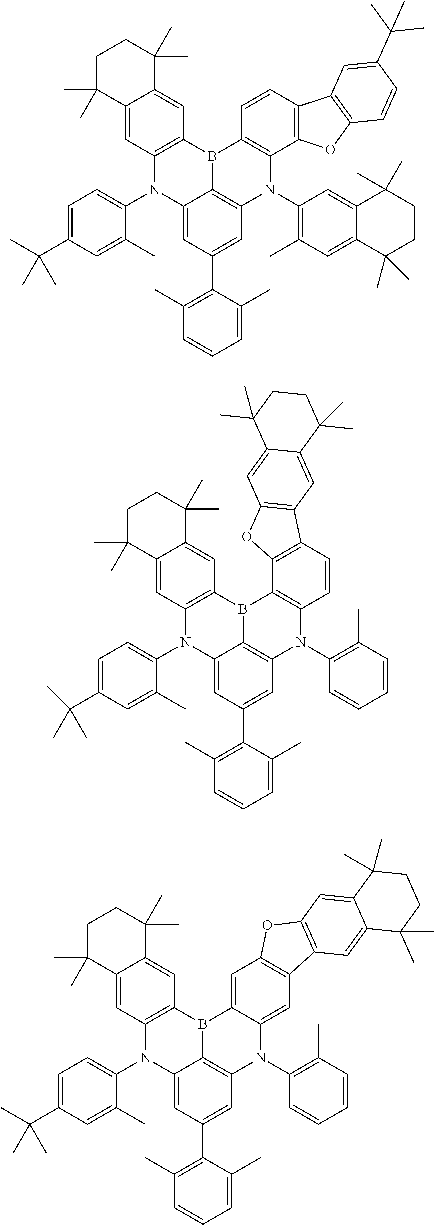

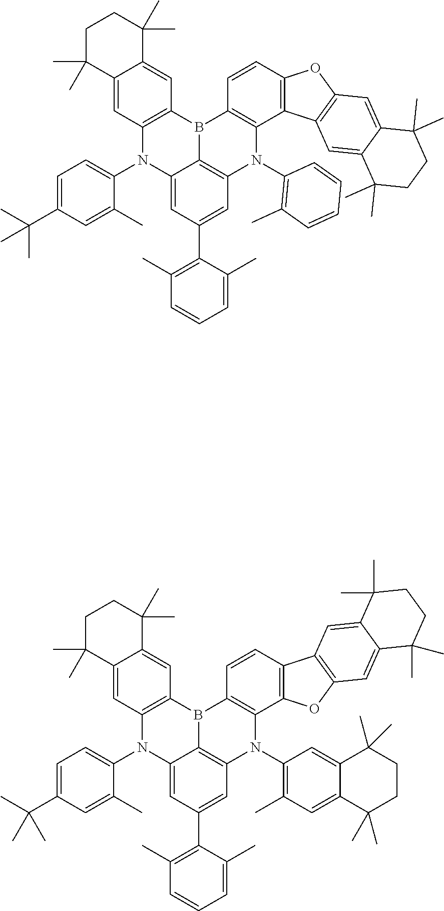

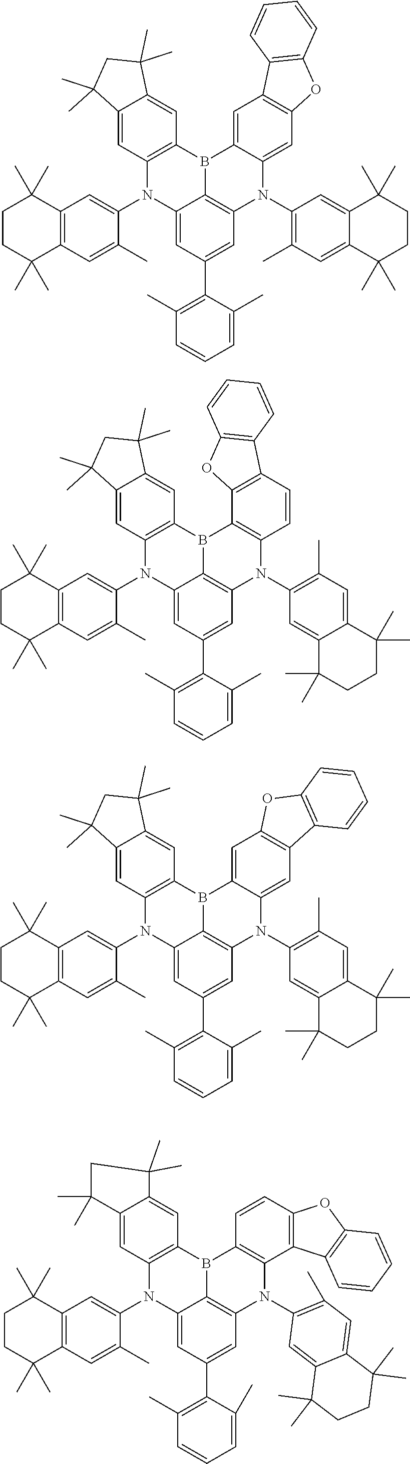

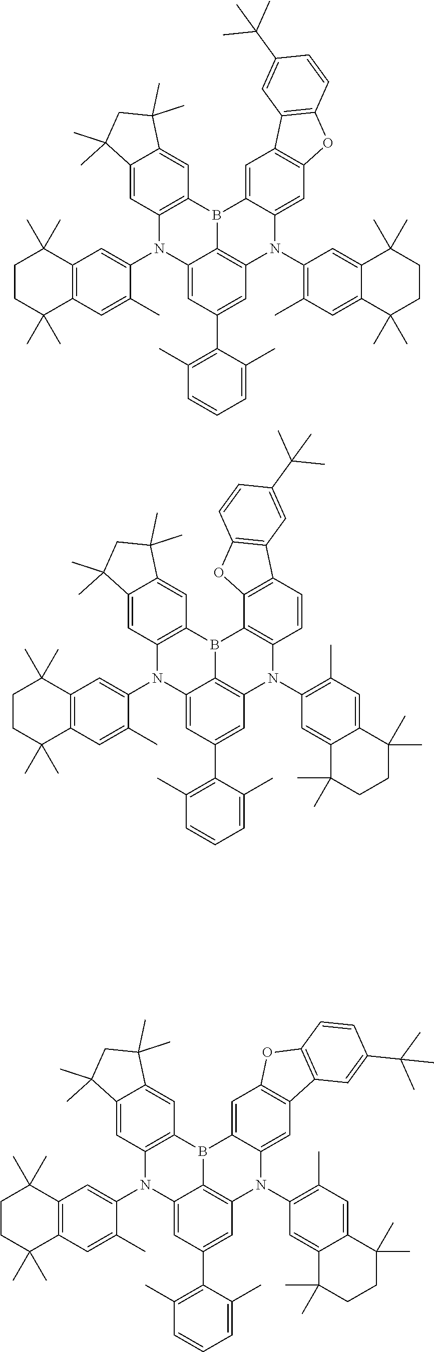

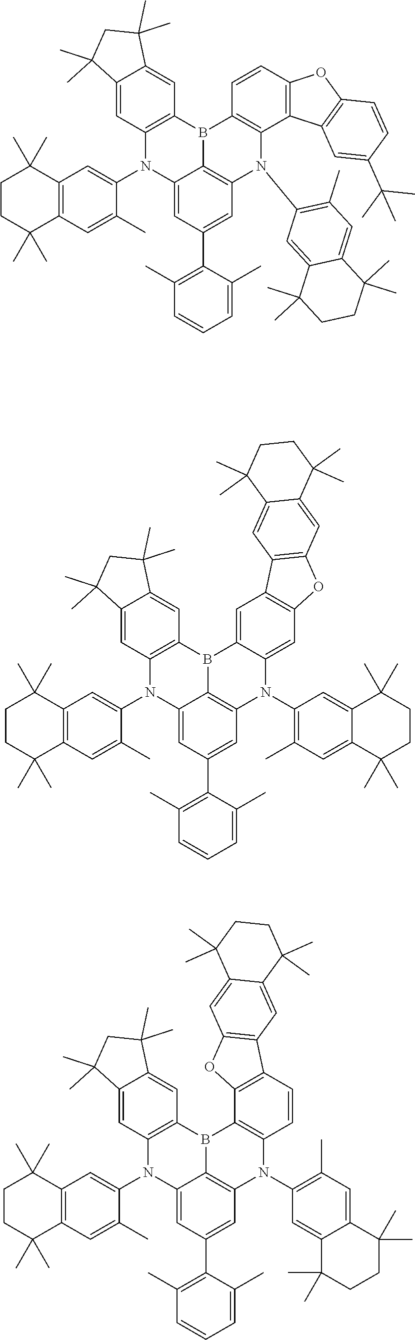 [SMILES: Cc1cc2c(cc1N1c3cc4c(cc3B3c5ccc6oc7ccc(C(C)(C)C)cc7c6c5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(-c7c(C)cccc7C)cc1c53)oc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(-c1c(C)cccc1C)cc5N(c1cc5c(cc1C)C(C)(C)CCC5(C)C)c1ccc5c(oc6cc7c(cc65)C(C)(C)CCC7(C)C)c13)C(C)(C)CC4(C)C)C(C)(C)CCC2(C)C]

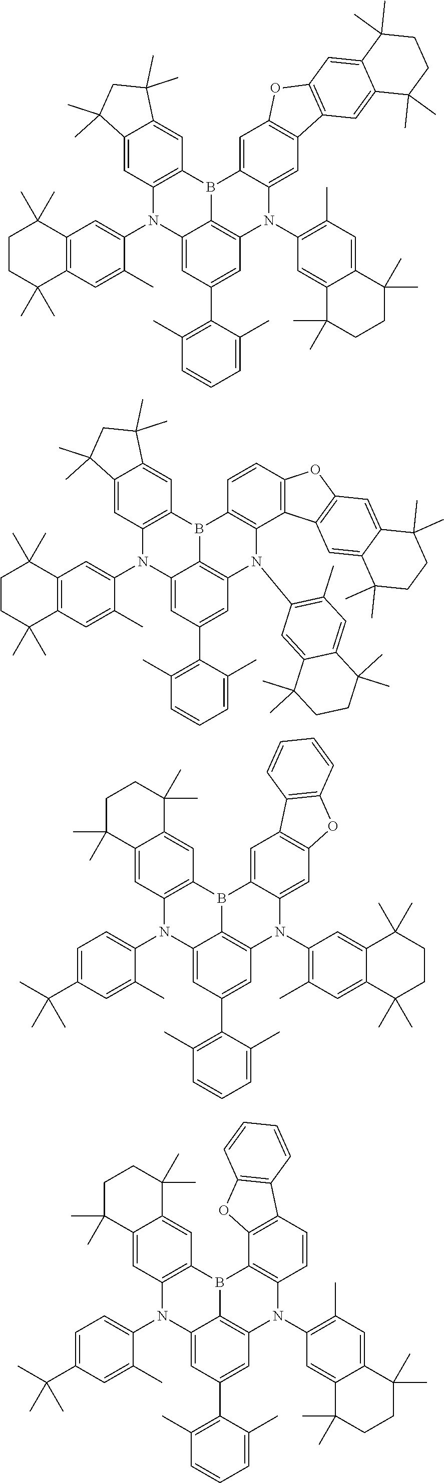

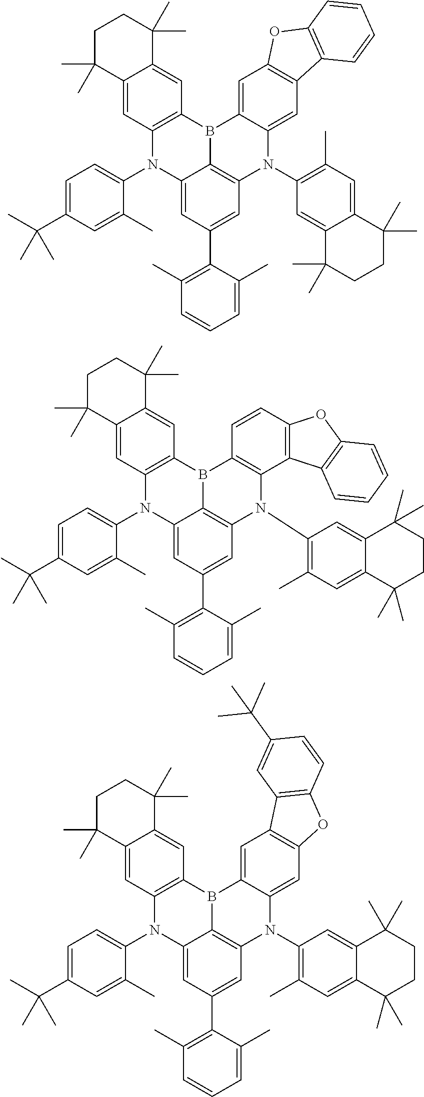

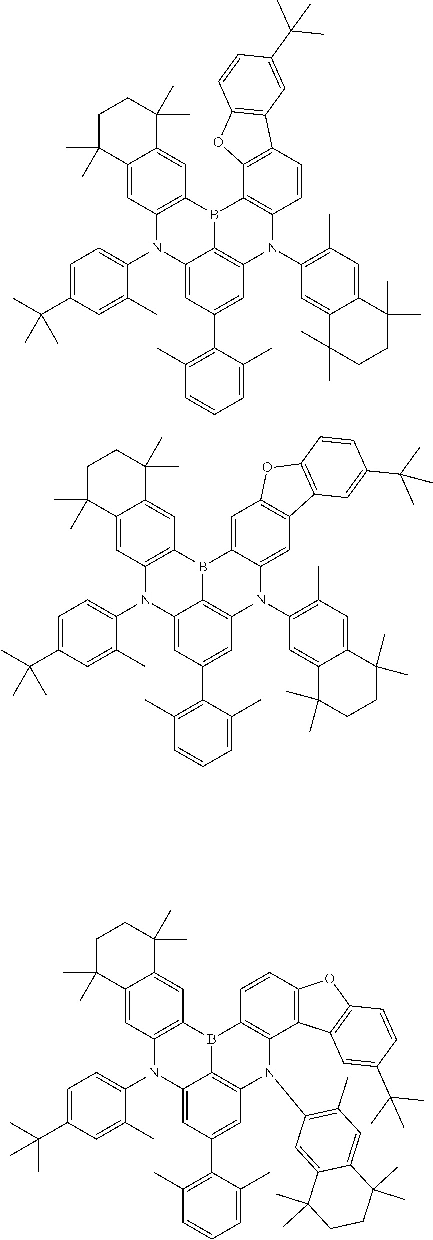

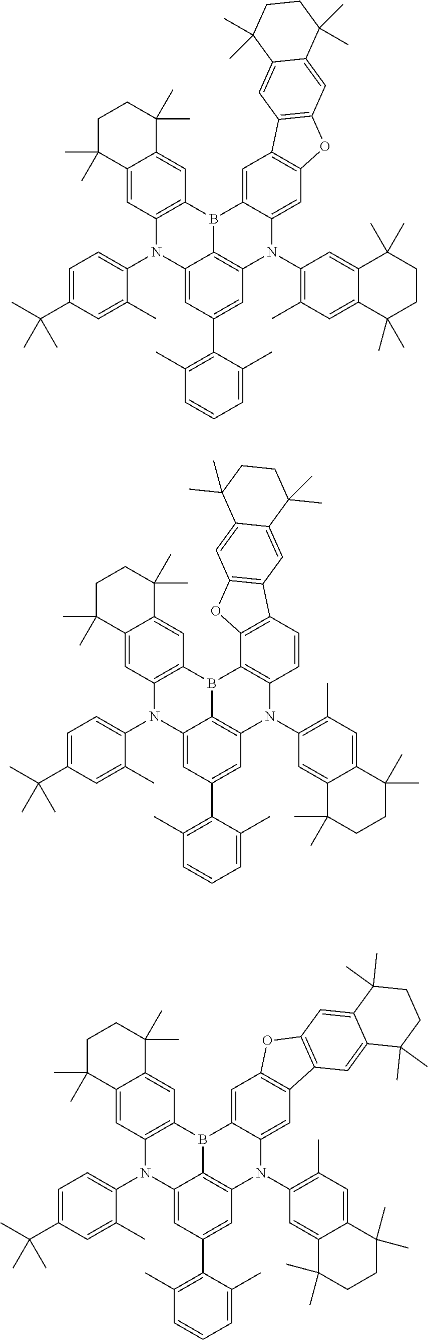

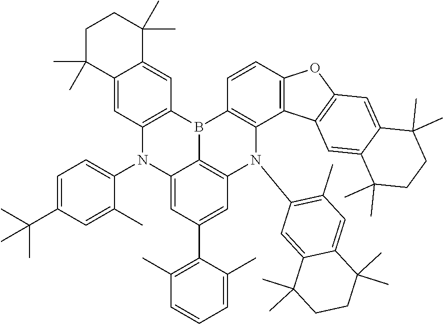 [SMILES: Cc1cc(C(C)(C)C)ccc1N1c2cc3c(cc2B2c4ccc5oc6cc7c(cc6c5c4N(c4cc5c(cc4C)C(C)(C)CCC5(C)C)c4cc(-c5c(C)cccc5C)cc1c42)C(C)(C)CCC7(C)C)C(C)(C)CCC3(C)C]

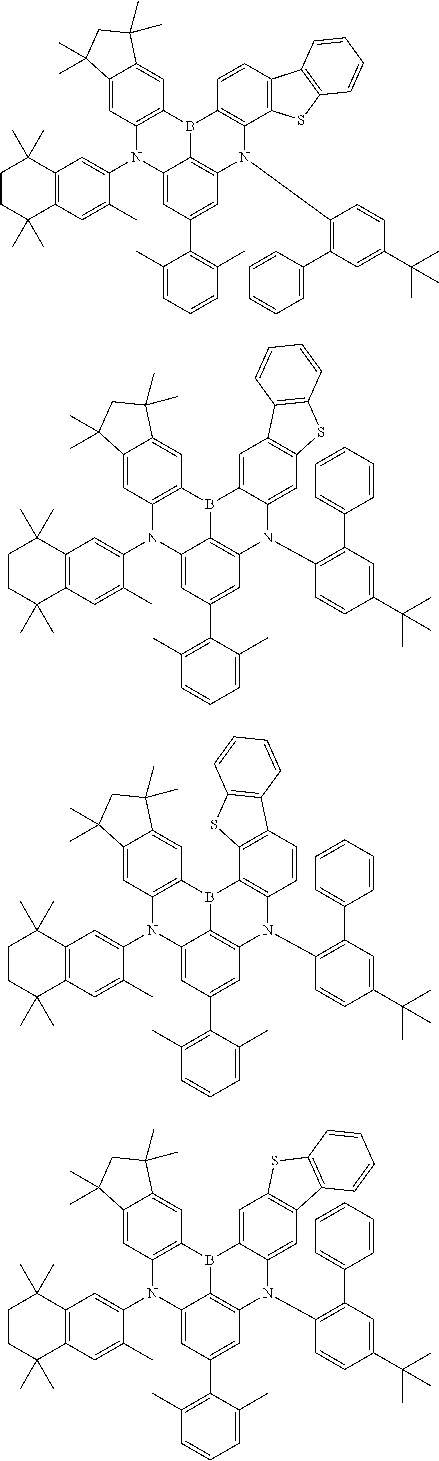

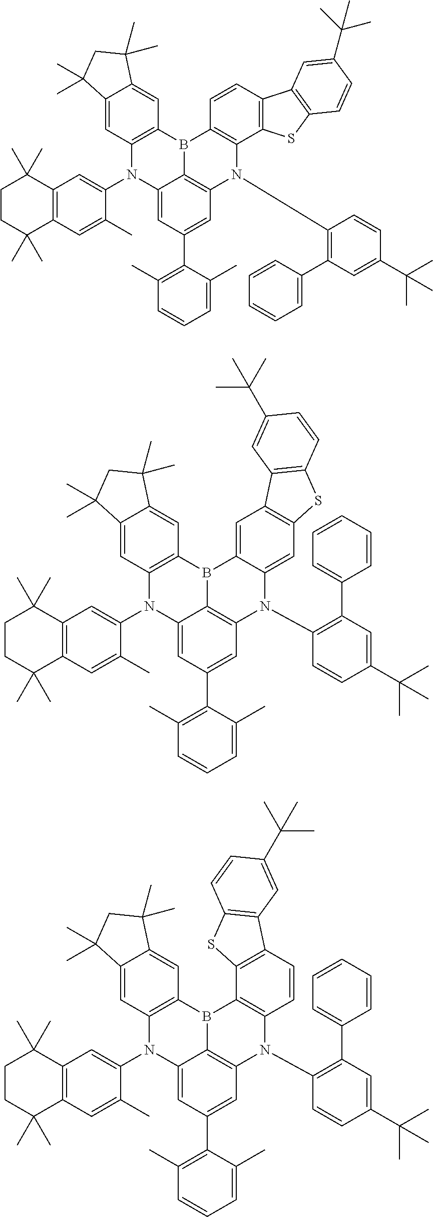

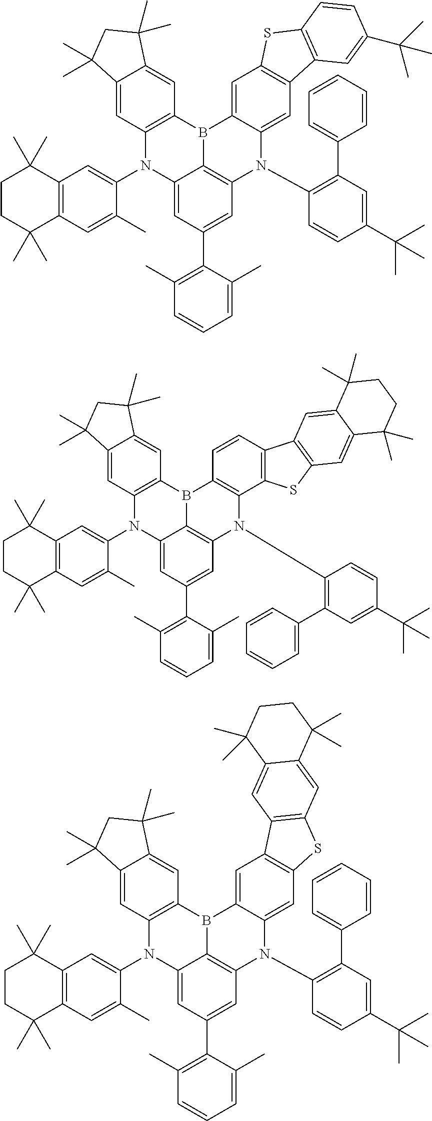

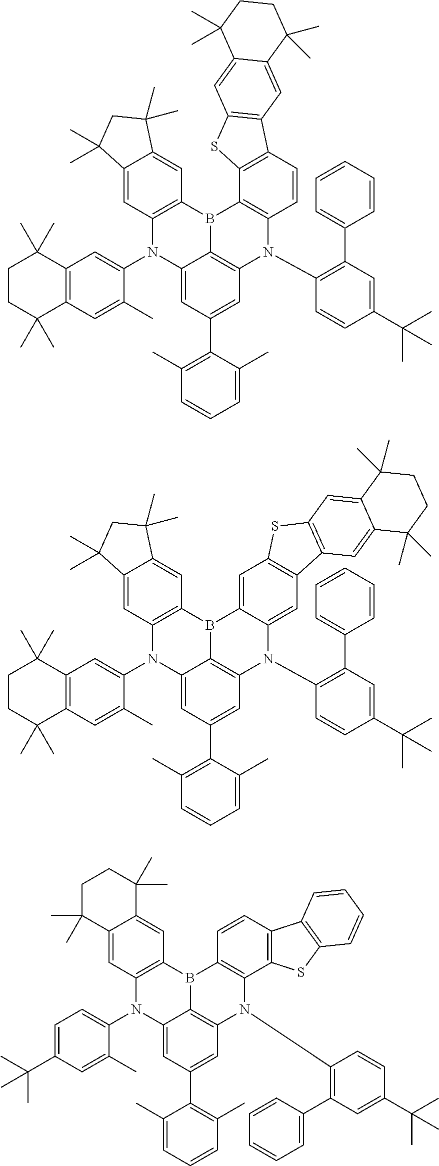

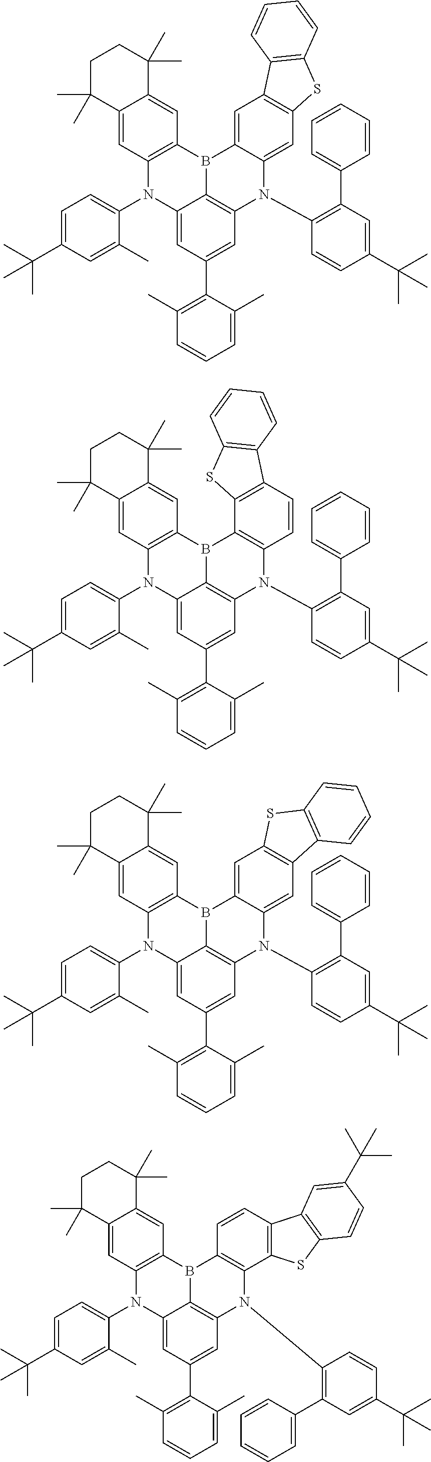

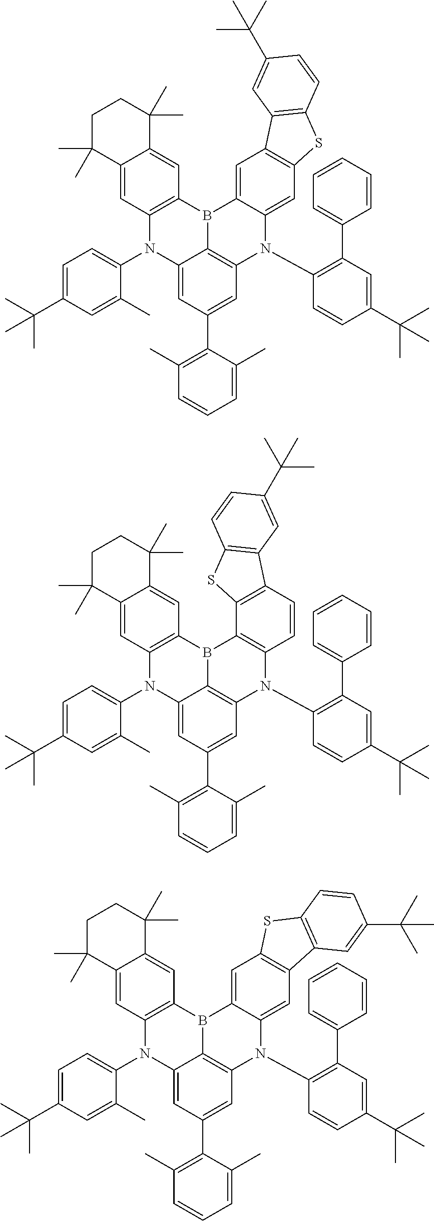

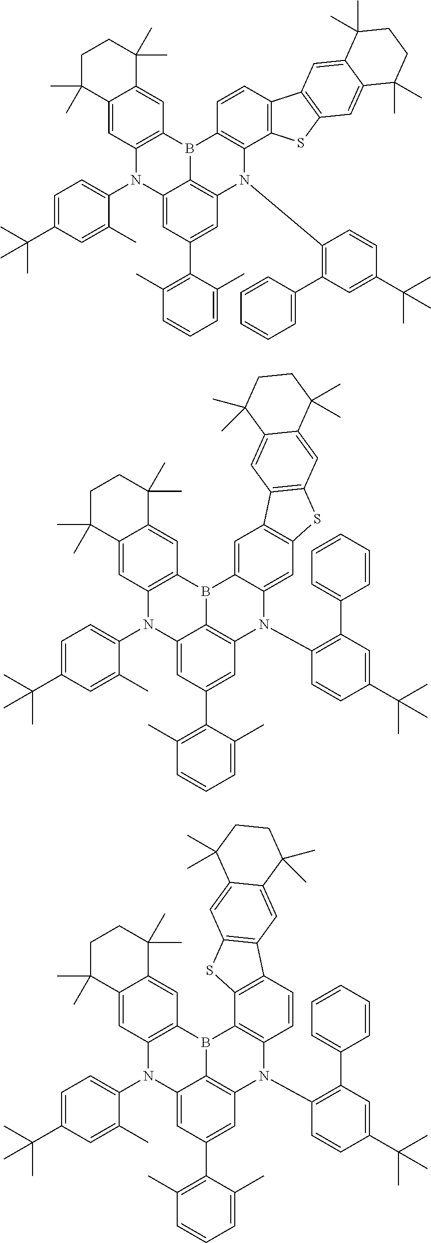

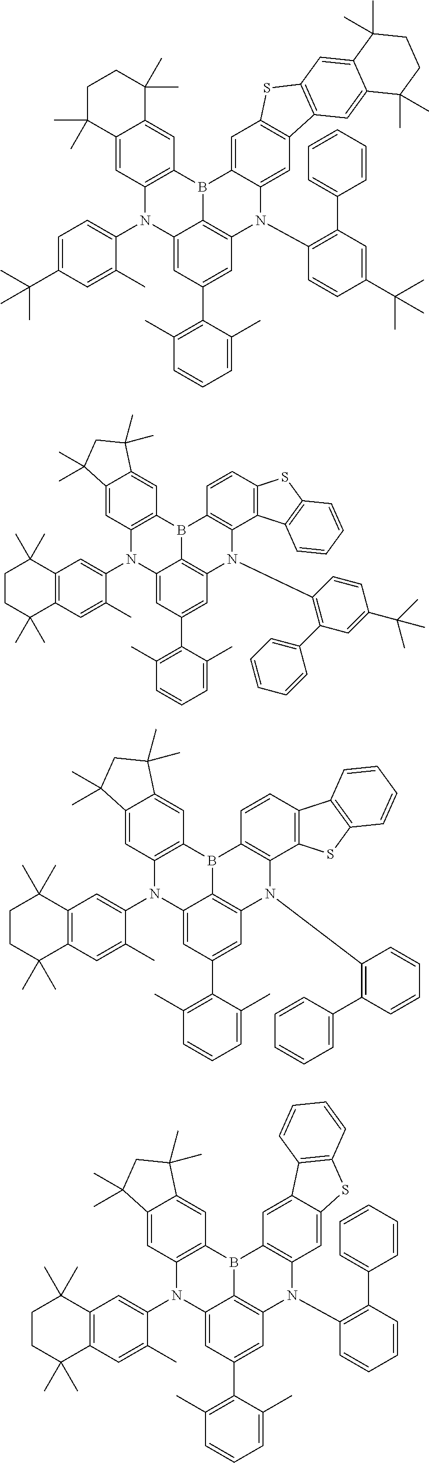

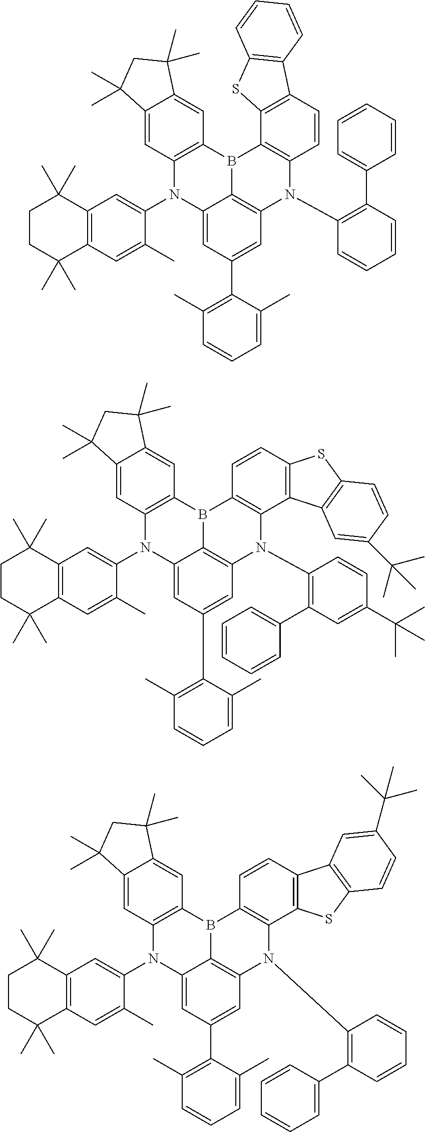 [SMILES: Cc1cc2c(cc1N1c3cc4c(cc3B3c5c1cc(-c1c(C)cccc1C)cc5N(c1ccccc1-c1ccccc1)c1ccc5c(sc6ccccc65)c13)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(-c6c(C)cccc6C)cc1c53)C(C)(C)CC4(C)C)C(C)(C)CCC2(C)C]

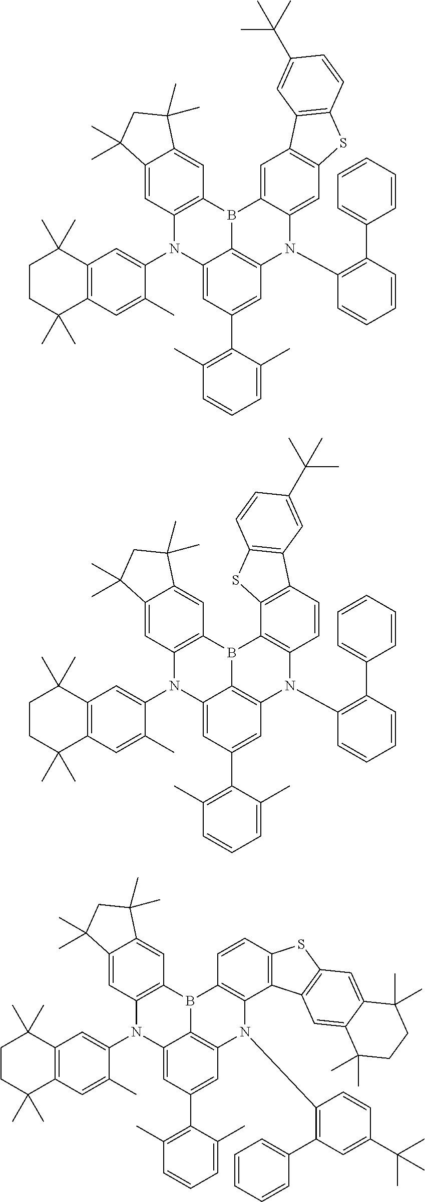 [SMILES: Cc1cc2c(cc1N1c3cc4c(cc3B3c5cc6c(cc5N(c5ccccc5-c5ccccc5)c5cc(-c7c(C)cccc7C)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(-c6c(C)cccc6C)cc1c53)C(C)(C)CCC8(C)C)C(C)(C)CC4(C)C)C(C)(C)CCC2(C)C]

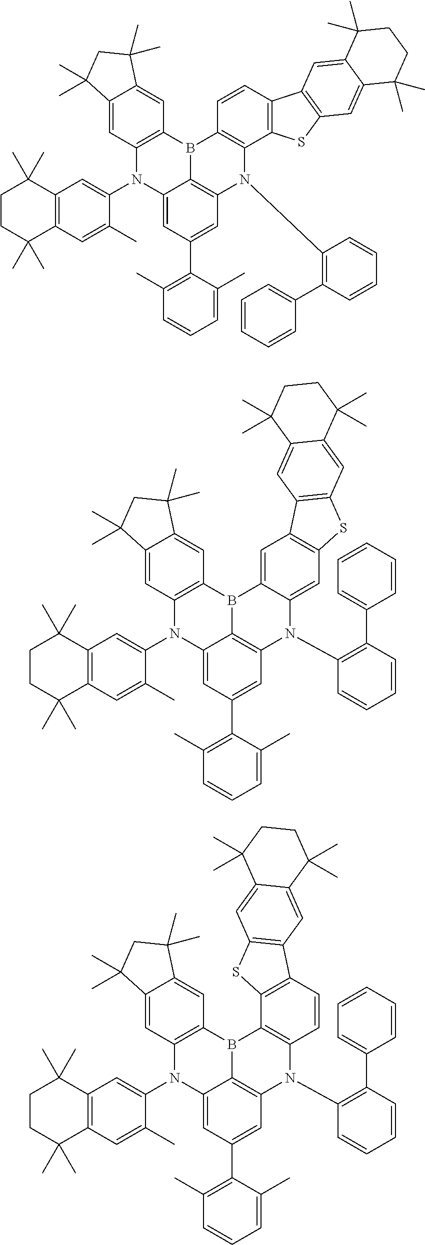

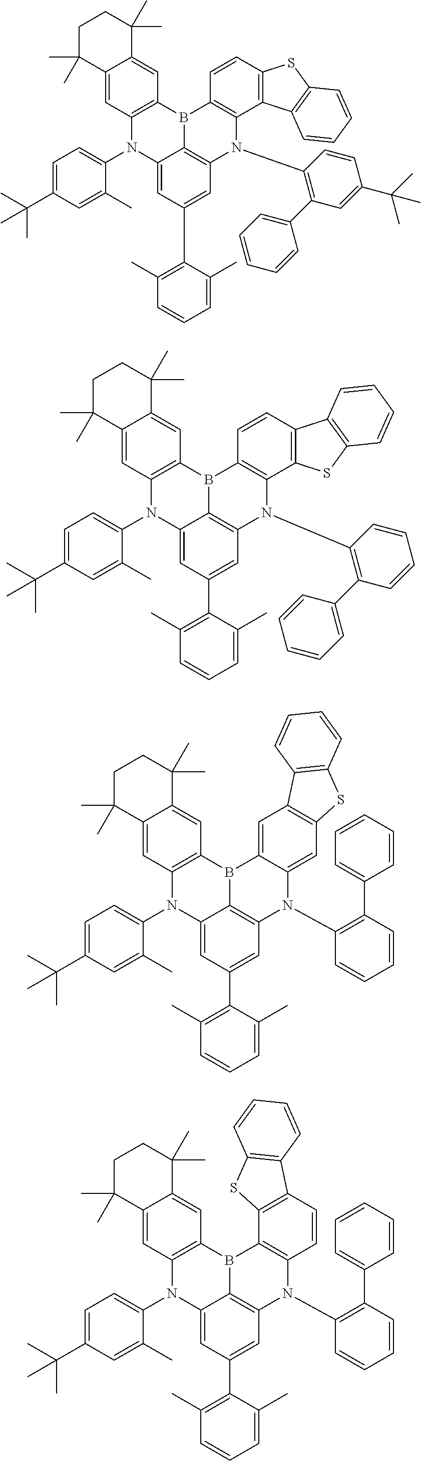

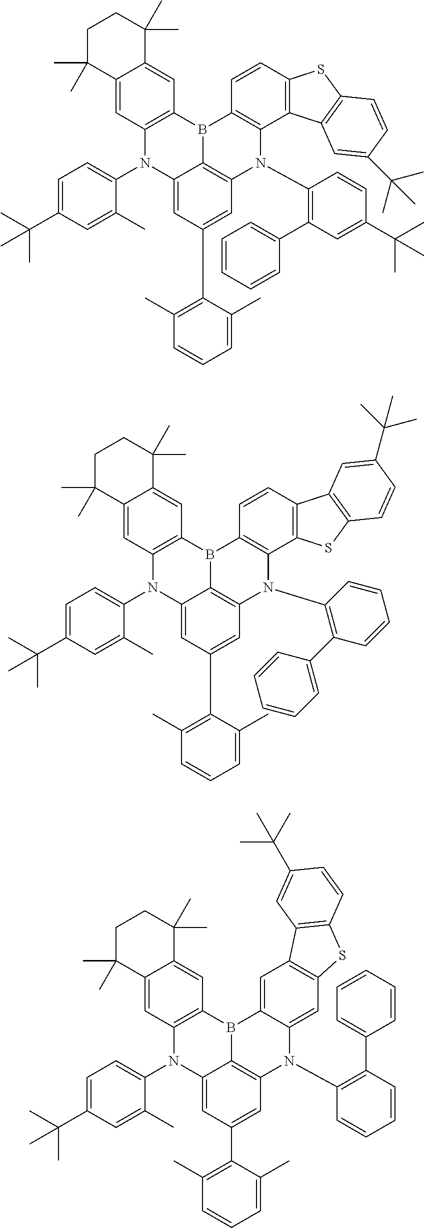

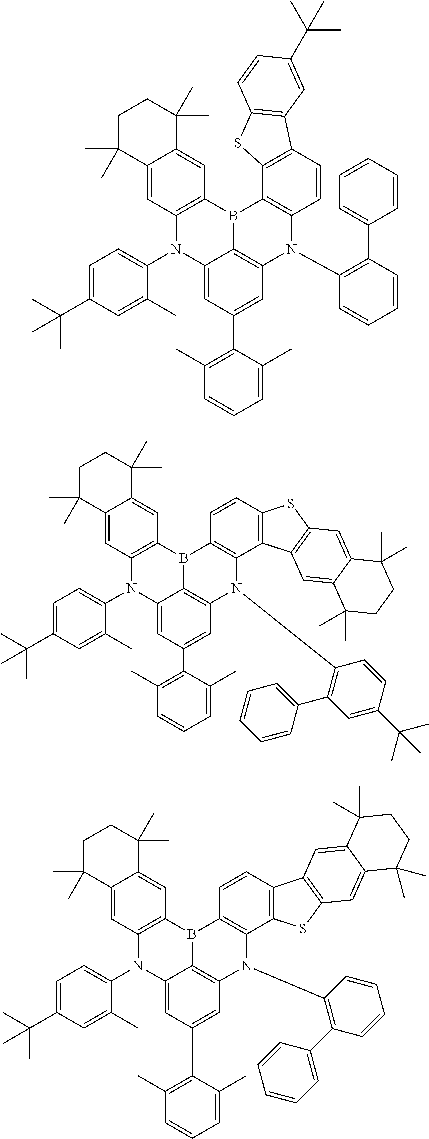

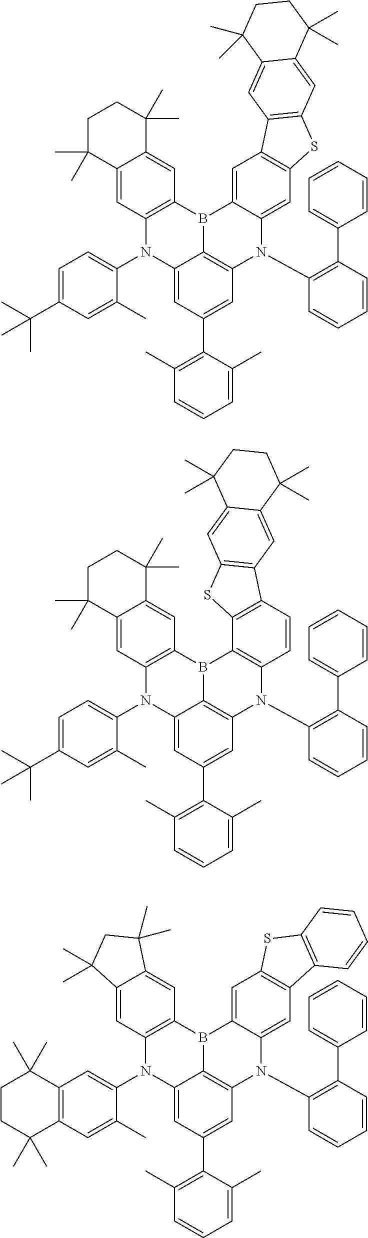

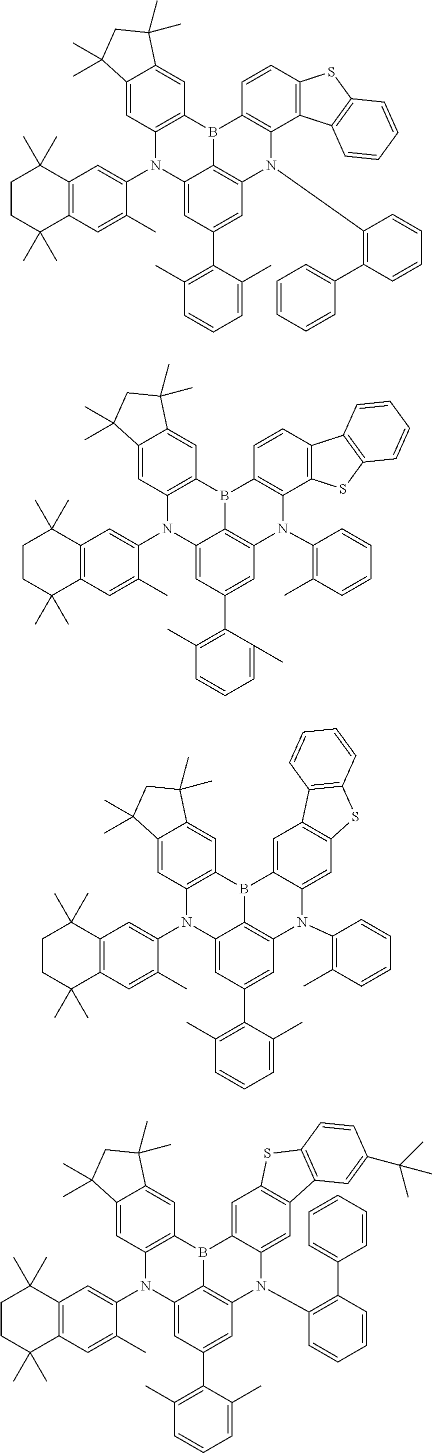 [SMILES: Cc1cc2c(cc1N1c3cc4c(cc3B3c5ccc6sc7ccccc7c6c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5C)c5cc(-c6c(C)cccc6C)cc1c53)C(C)(C)CC4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(-c5c(C)cccc5C)cc1c32)C(C)(C)CC4(C)C ; Cc1cc2c(cc1N1c3cc4c(cc3B3c5cc6sc7ccc(C(C)(C)C)cc7c6cc5N(c5ccccc5-c5ccccc5)c5cc(-c6c(C)cccc6C)cc1c53)C(C)(C)CC4(C)C)C(C)(C)CCC2(C)C]

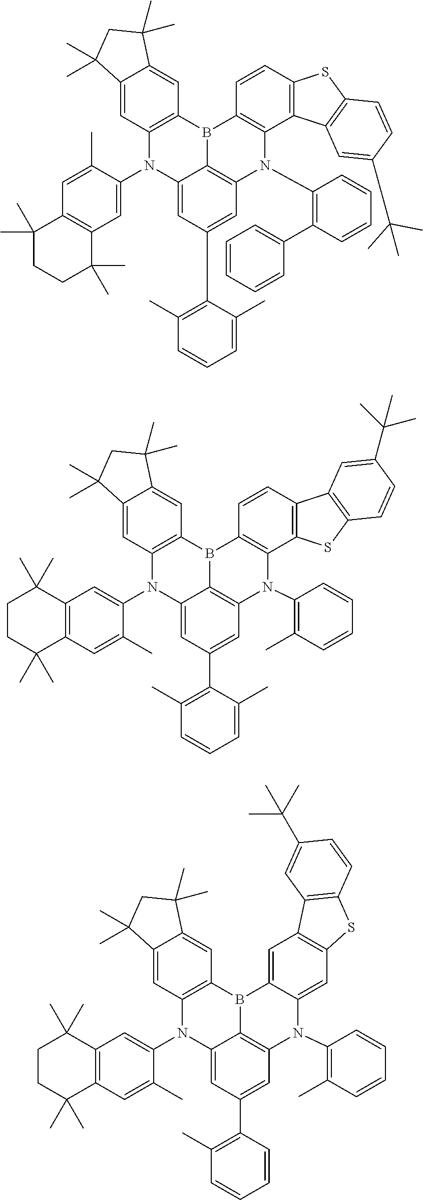 [SMILES: Cc1cc2c(cc1N1c3cc4c(cc3B3c5ccc6sc7ccc(C(C)(C)C)cc7c6c5N(c5ccccc5-c5ccccc5)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5C)c5cc(-c6c(C)cccc6C)cc1c53)C(C)(C)CC4(C)C)C(C)(C)CCC2(C)C ; Cc1ccccc1-c1cc2c3c(c1)N(c1ccccc1C)c1cc4sc5ccc(C(C)(C)C)cc5c4cc1B3c1cc3c(cc1N2c1cc2c(cc1C)C(C)(C)CCC2(C)C)C(C)(C)CC3(C)C]

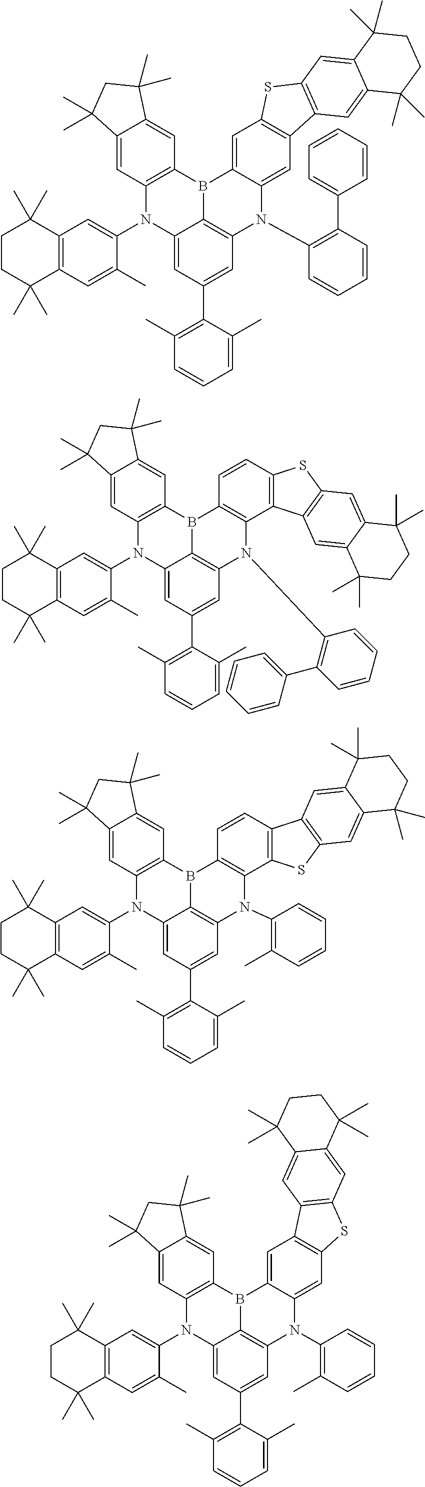

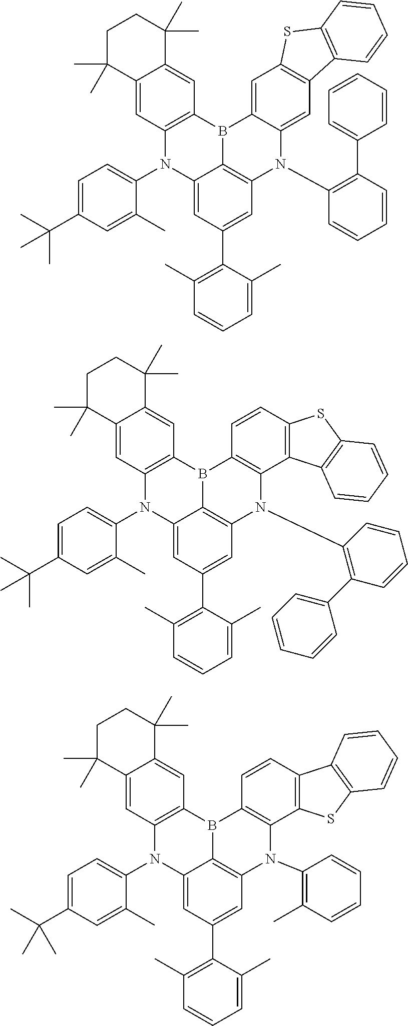

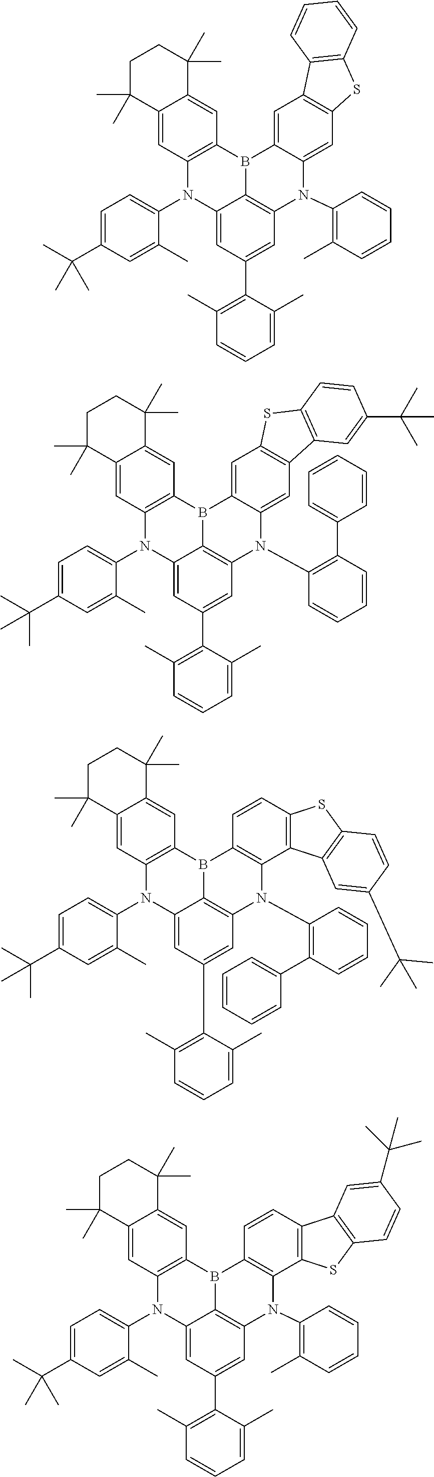

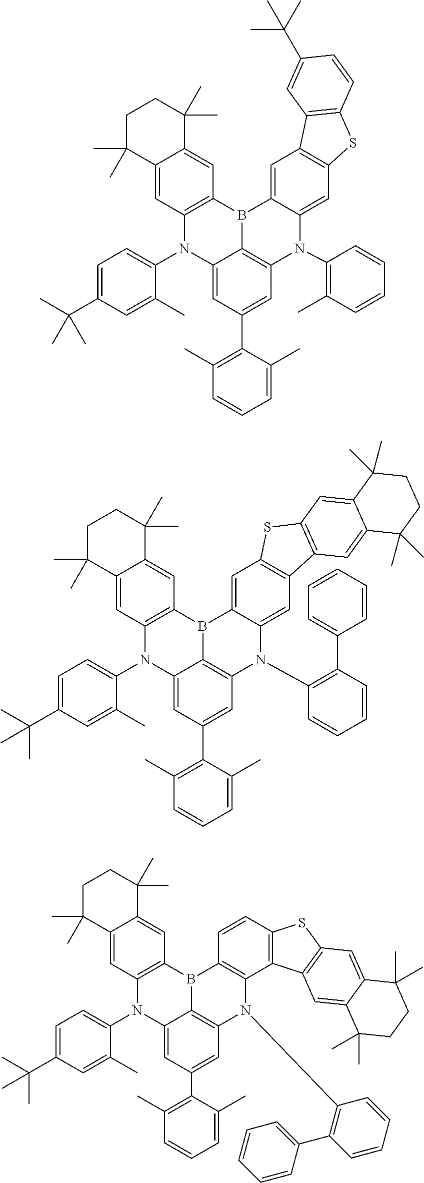

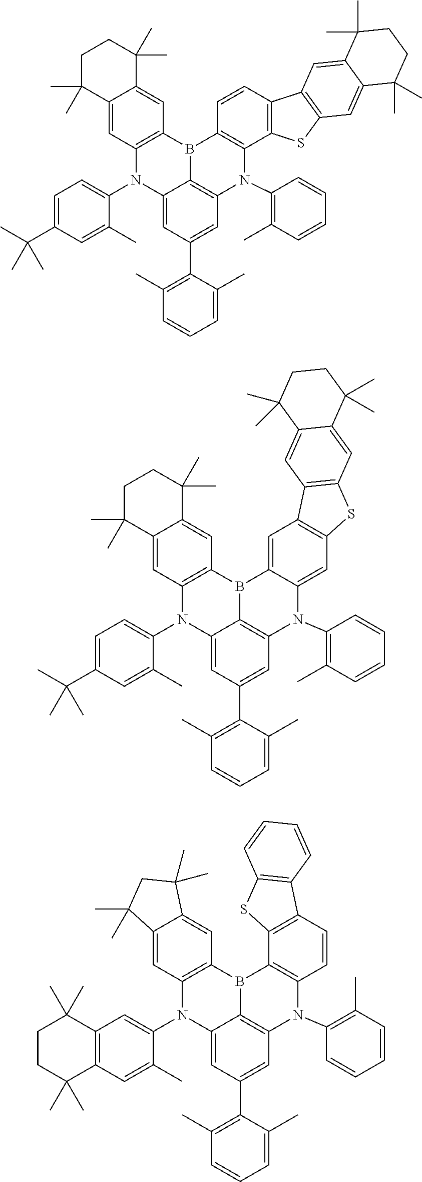

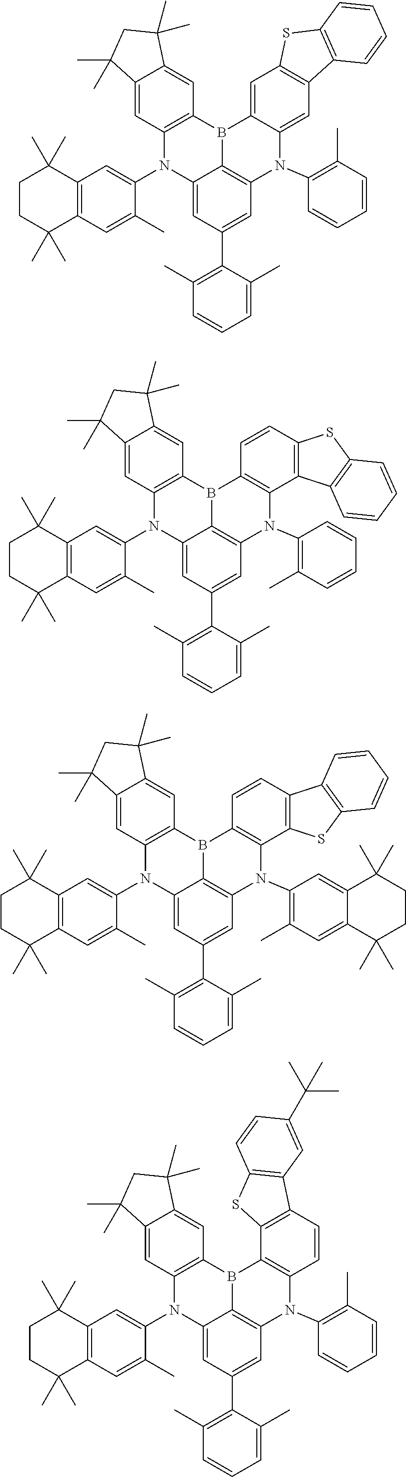 [SMILES: Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)sc1ccccc13 ; Cc1cc2c(cc1N1c3cc4c(cc3B3c5ccc6sc7ccccc7c6c5N(c5ccccc5C)c5cc(-c6c(C)cccc6C)cc1c53)C(C)(C)CC4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(-c6c(C)cccc6C)cc1c53)C(C)(C)CC4(C)C)C(C)(C)CCC2(C)C ; Cc1cc2c(cc1N1c3cc4c(cc3B3c5c1cc(-c1c(C)cccc1C)cc5N(c1ccccc1C)c1ccc5c(sc6ccc(C(C)(C)C)cc65)c13)C(C)(C)CC4(C)C)C(C)(C)CCC2(C)C]

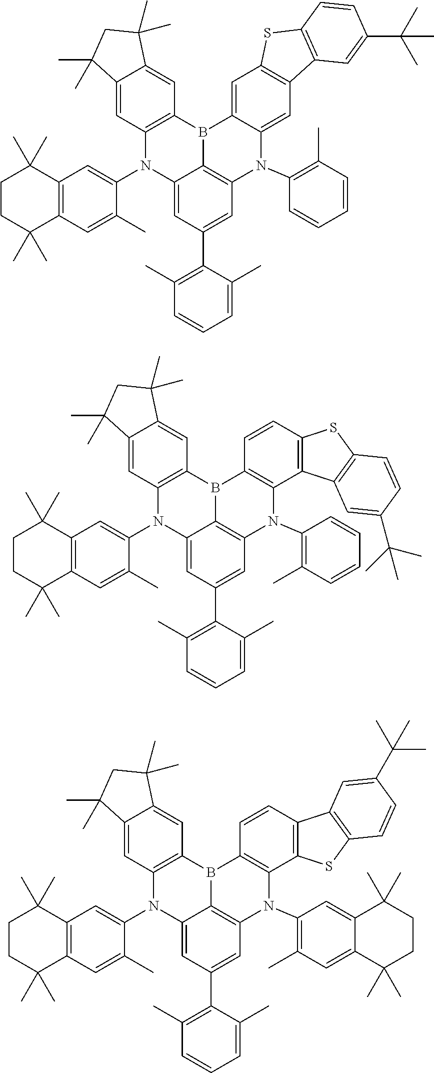

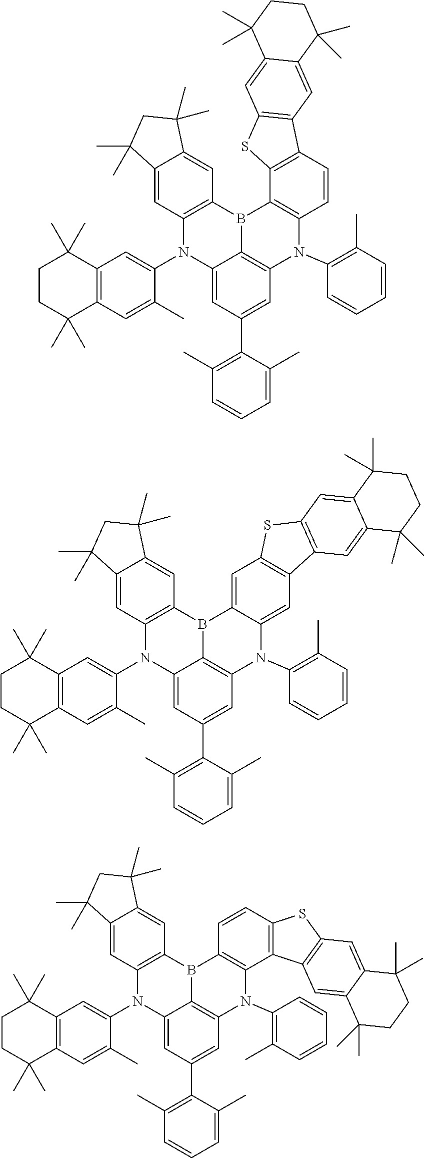 [SMILES: Cc1cc2c(cc1N1c3cc4c(cc3B3c5c1cc(-c1c(C)cccc1C)cc5N(c1ccccc1C)c1ccc5c(sc6cc7c(cc65)C(C)(C)CCC7(C)C)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(-c6c(C)cccc6C)cc1c42)C(C)(C)CC5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(-c6c(C)cccc6C)cc1c53)C(C)(C)CCC8(C)C)C(C)(C)CC4(C)C)C(C)(C)CCC2(C)C]

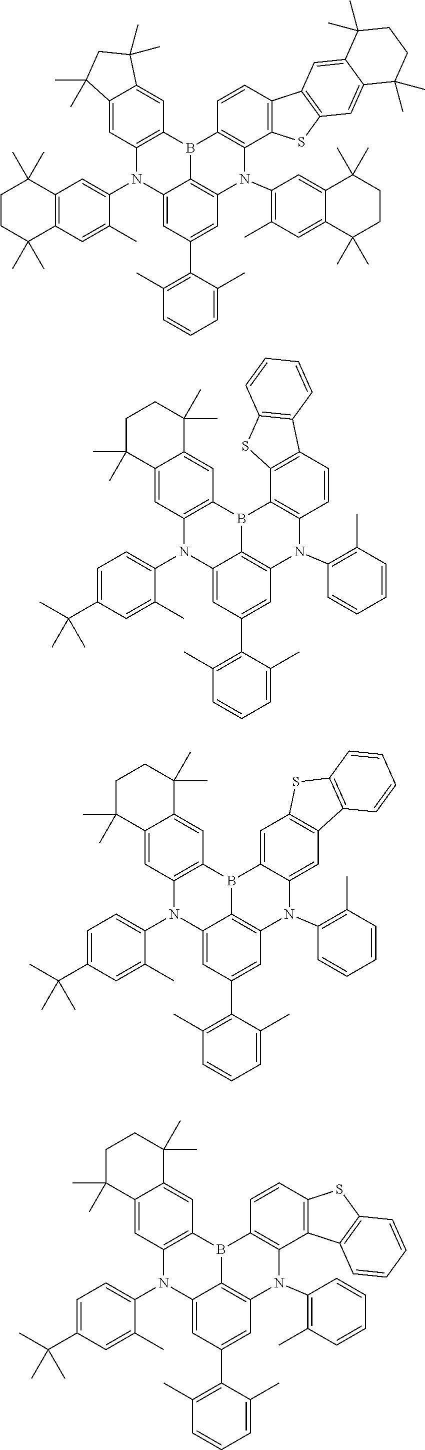

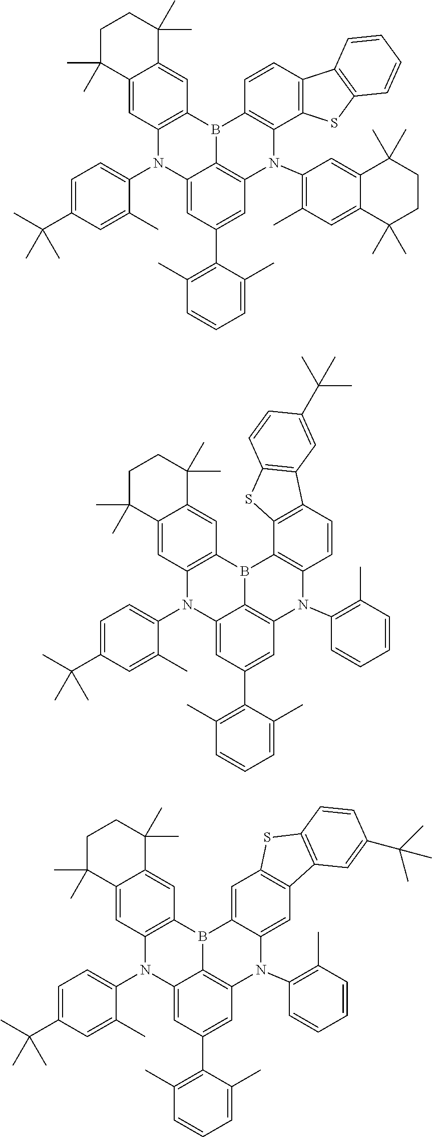 [SMILES: Cc1cc(C(C)(C)C)ccc1N1c2cc3c(cc2B2c4ccc5c(sc6ccccc65)c4N(c4cc5c(cc4C)C(C)(C)CCC5(C)C)c4cc(-c5c(C)cccc5C)cc1c42)C(C)(C)CCC3(C)C ; Cc1cc(C(C)(C)C)ccc1N1c2cc3c(cc2B2c4c1cc(-c1c(C)cccc1C)cc4N(c1ccccc1C)c1ccc4c(sc5ccc(C(C)(C)C)cc54)c12)C(C)(C)CCC3(C)C ; Cc1cc(C(C)(C)C)ccc1N1c2cc3c(cc2B2c4cc5sc6ccc(C(C)(C)C)cc6c5cc4N(c4ccccc4C)c4cc(-c5c(C)cccc5C)cc1c42)C(C)(C)CCC3(C)C]

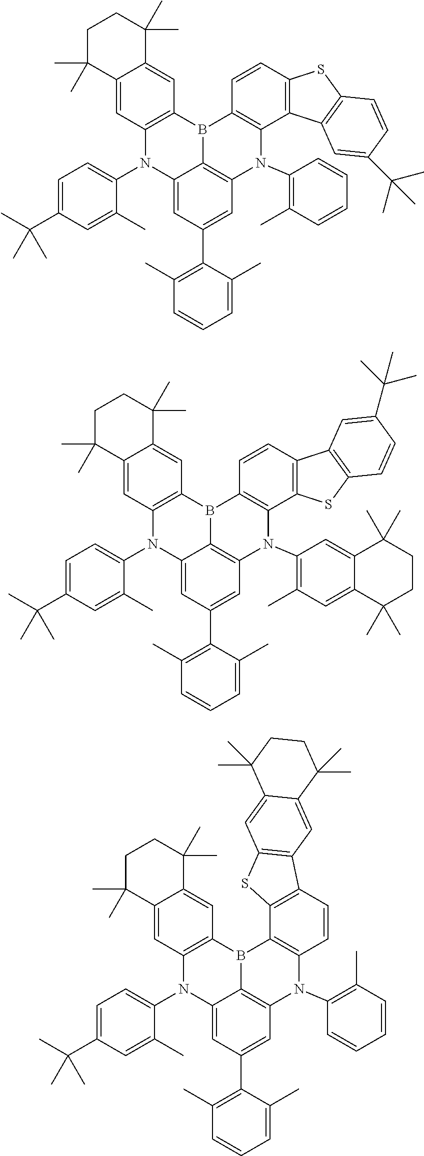

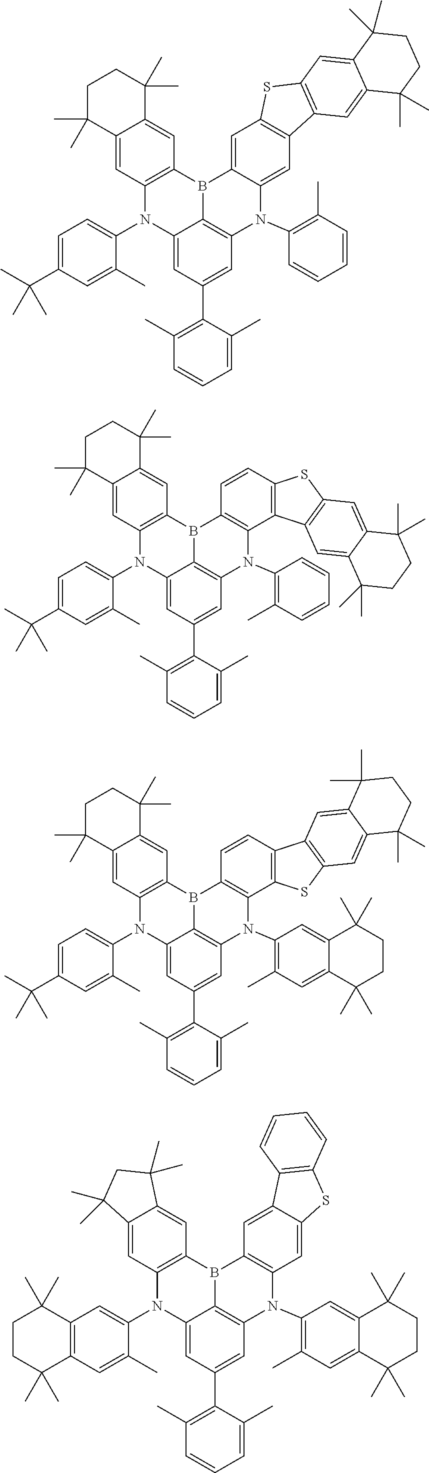

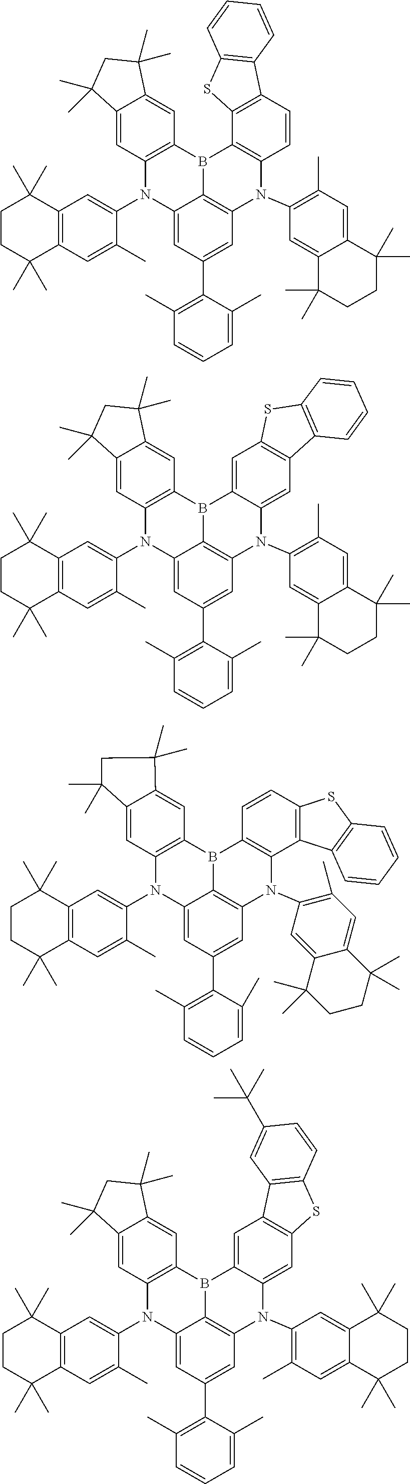

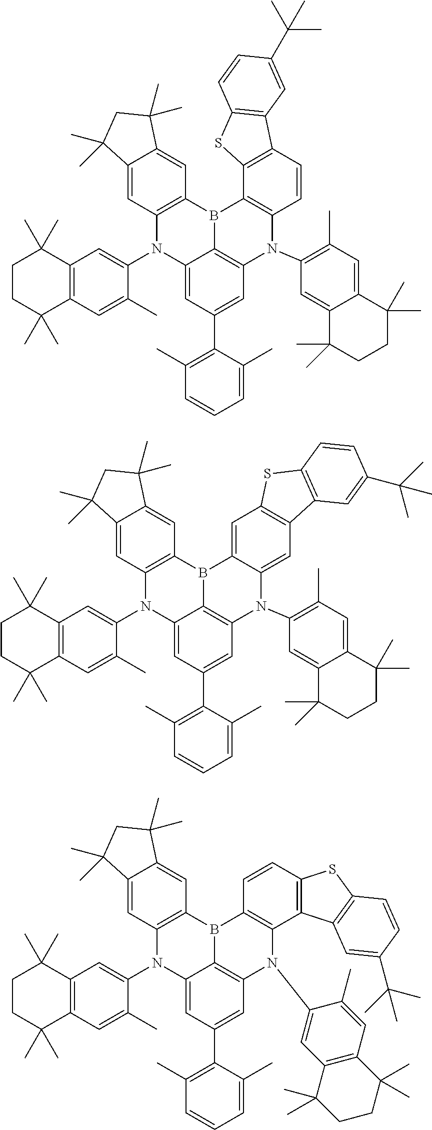

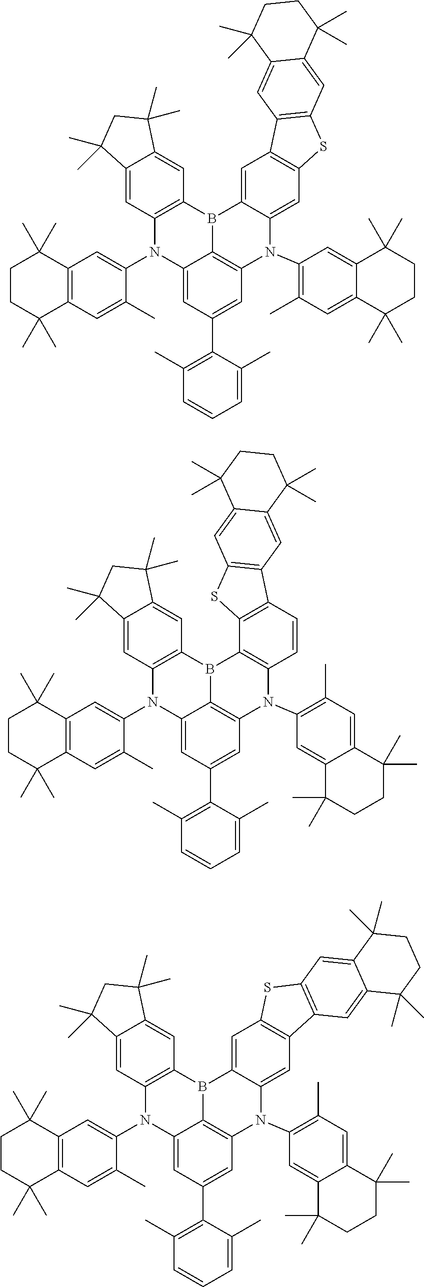

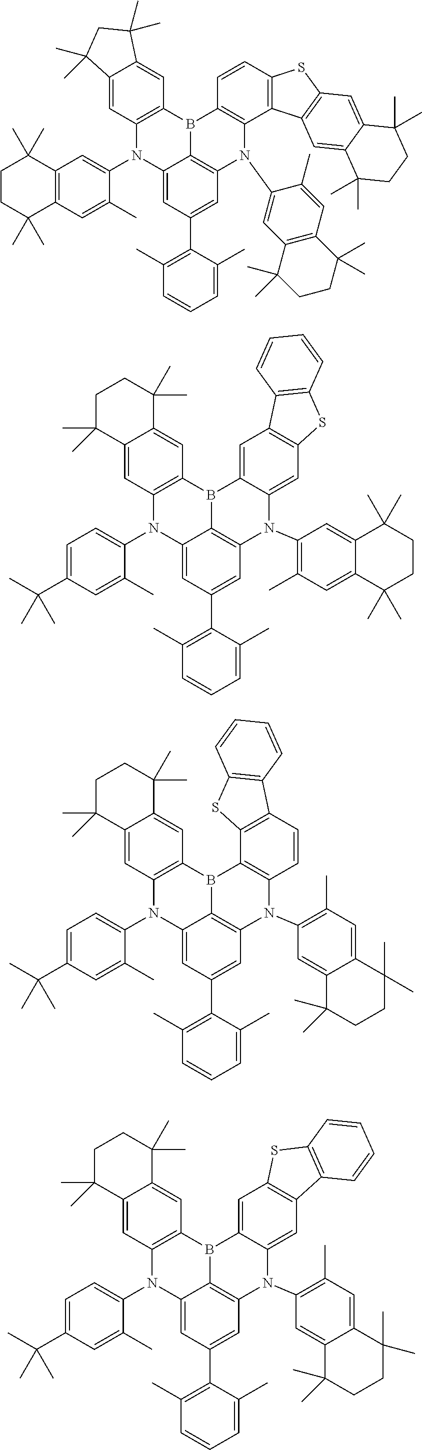

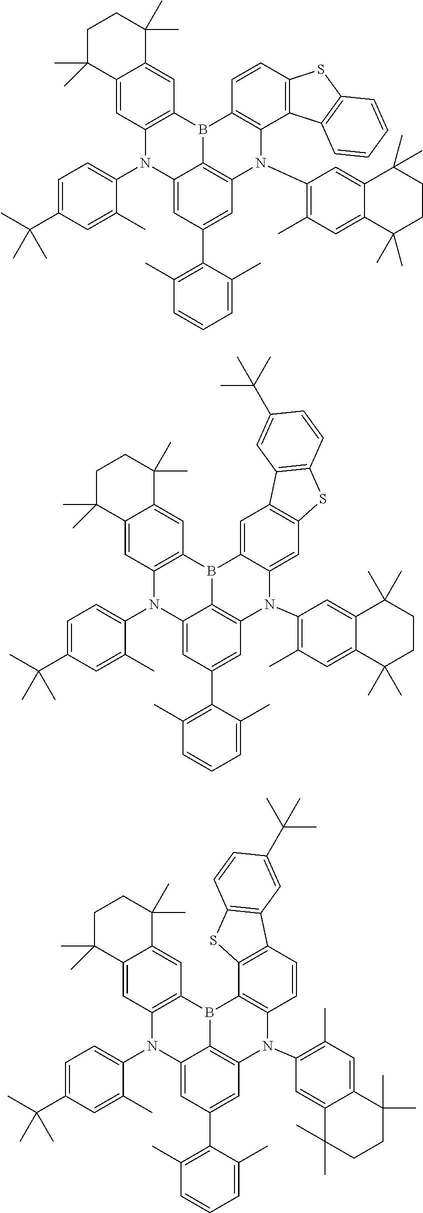

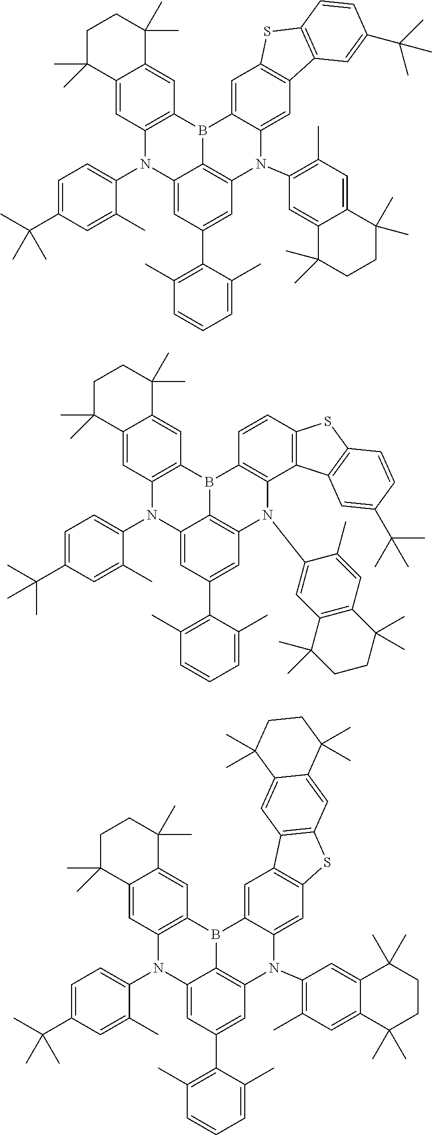

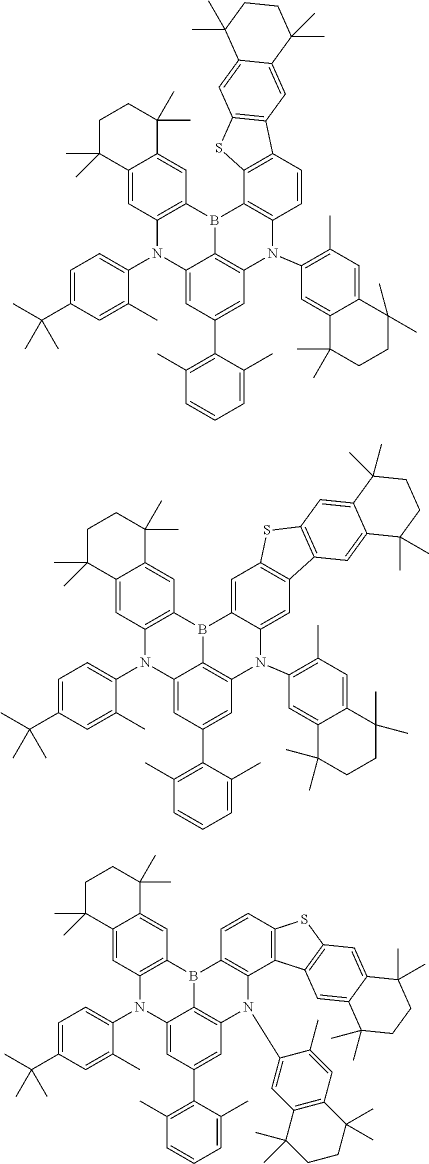

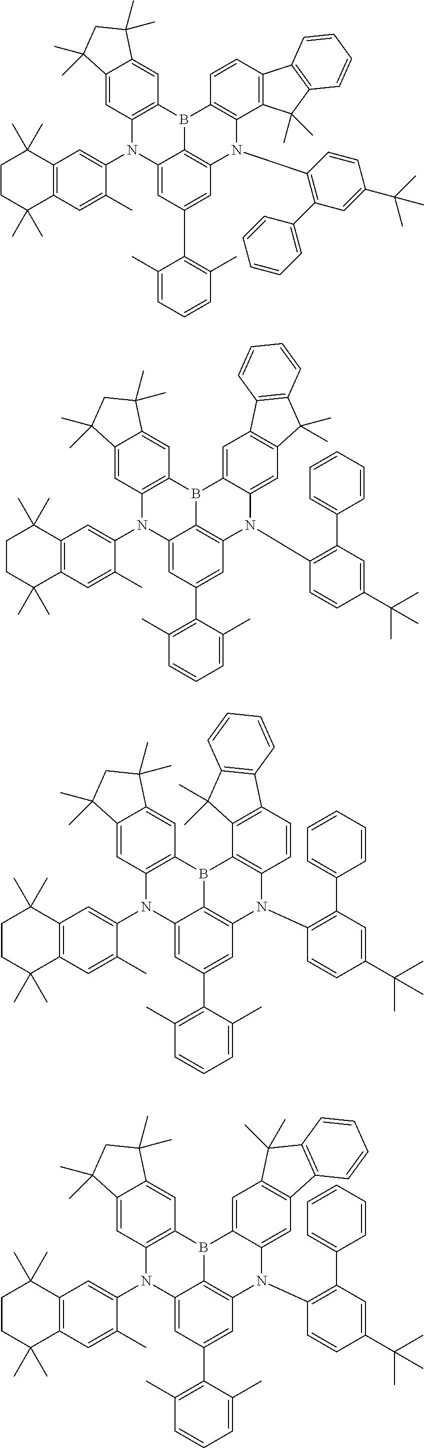

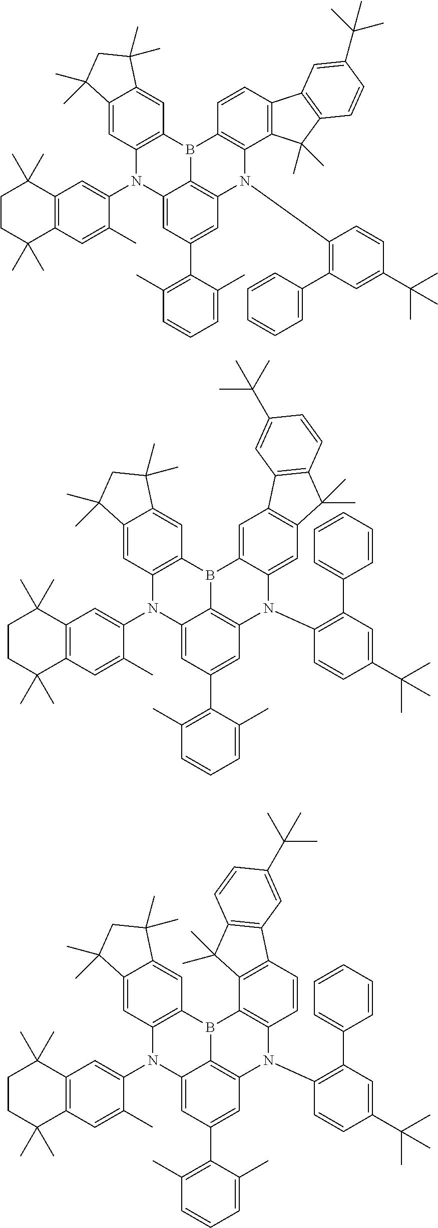

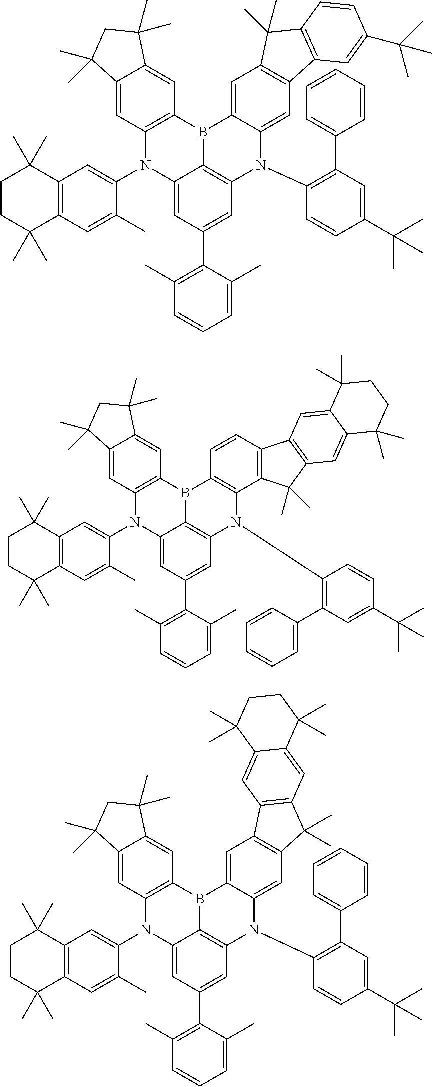

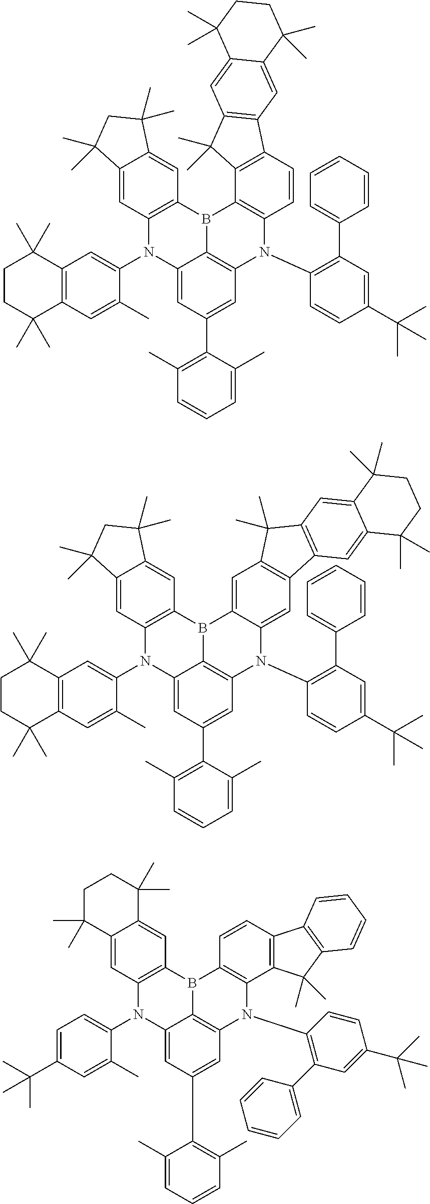

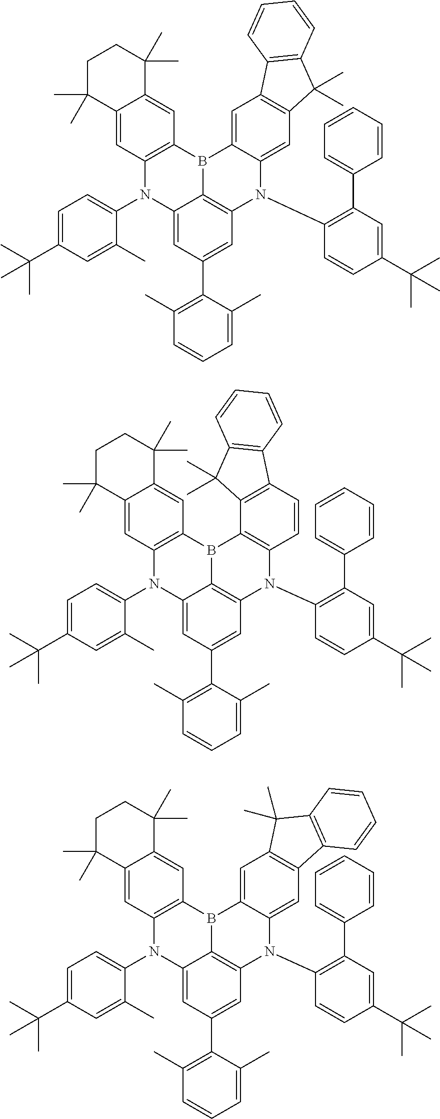

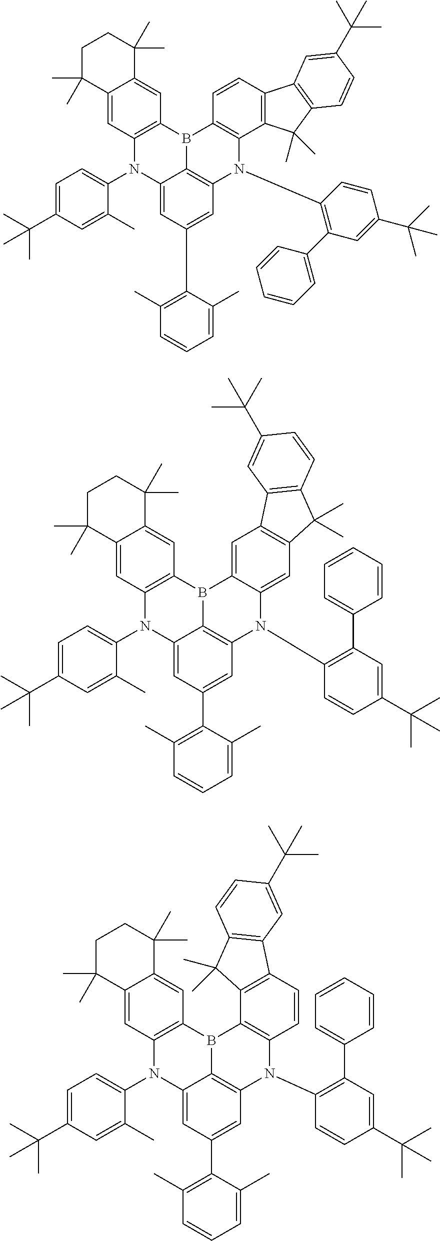

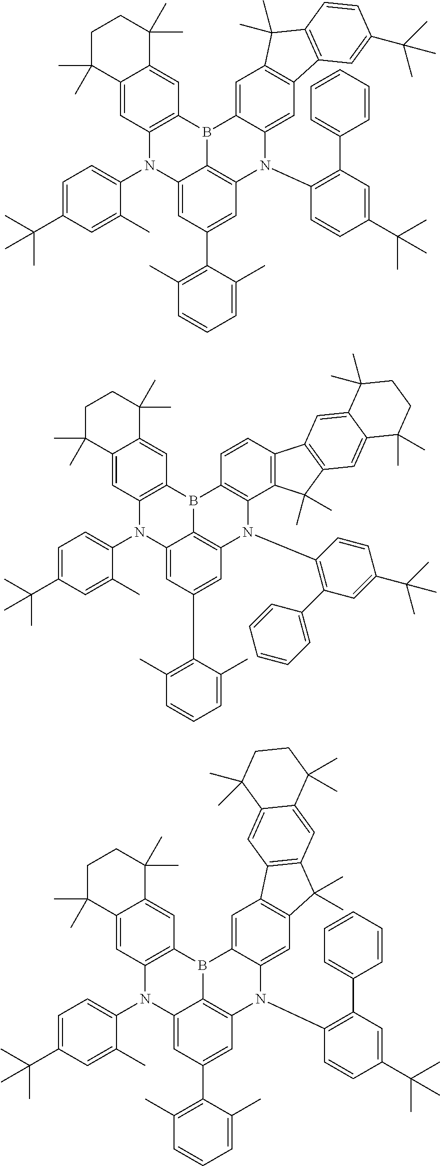

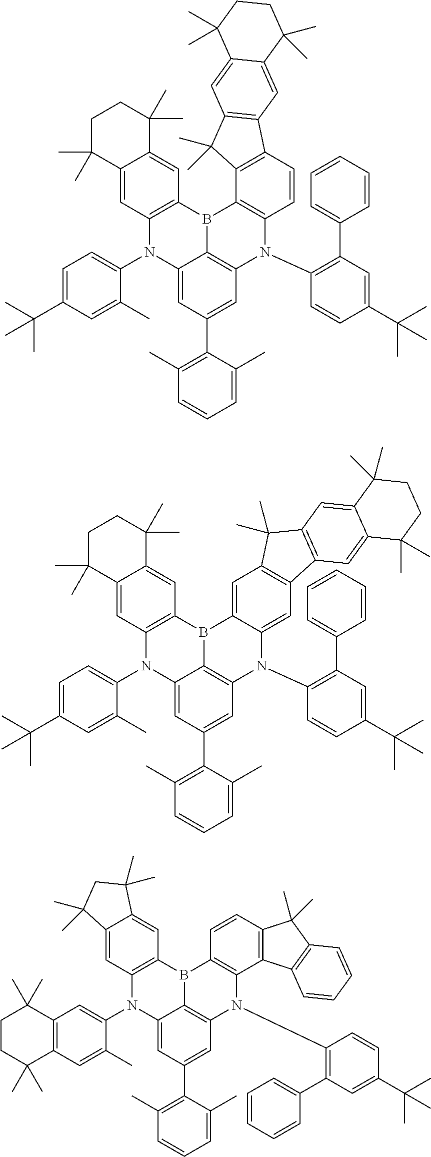

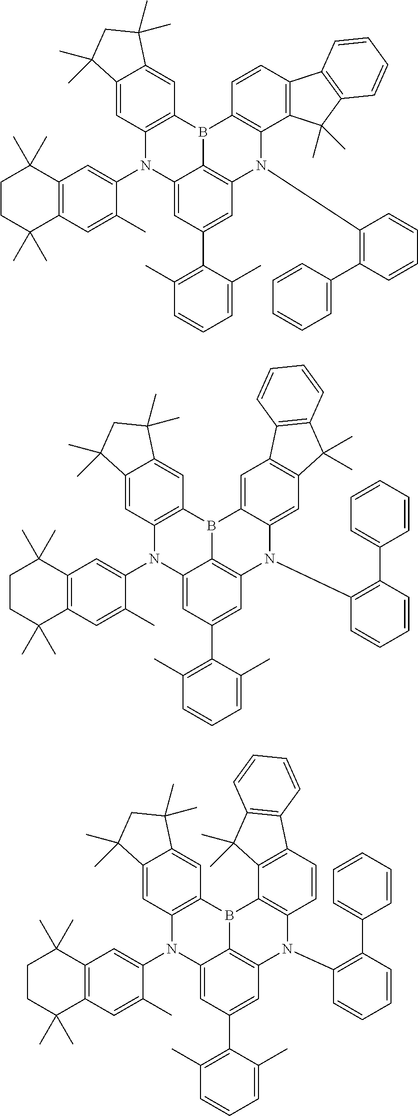

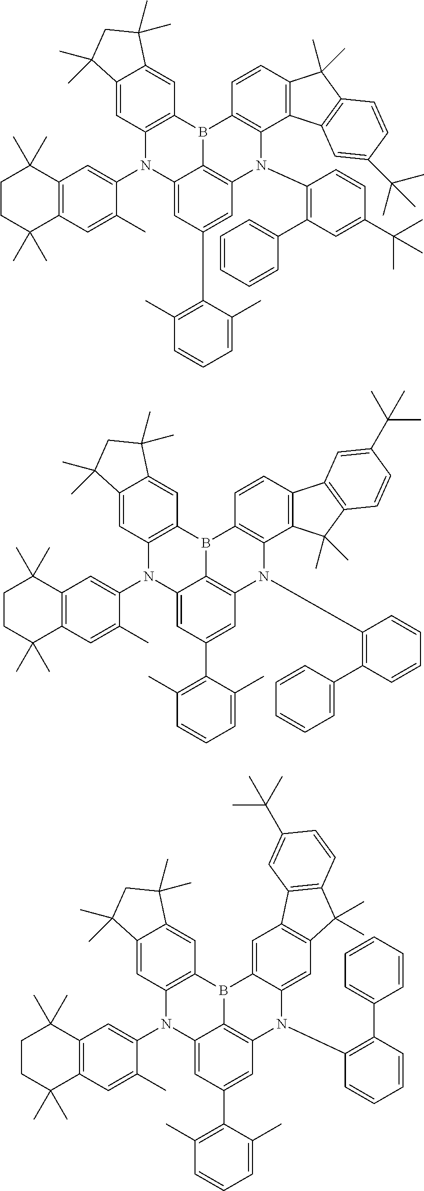 [SMILES: Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(-c7c(C)cccc7C)cc1c53)C(C)(C)c1ccc(C(C)(C)C)cc1-6)C(C)(C)CC4(C)C)C(C)(C)CCC2(C)C]

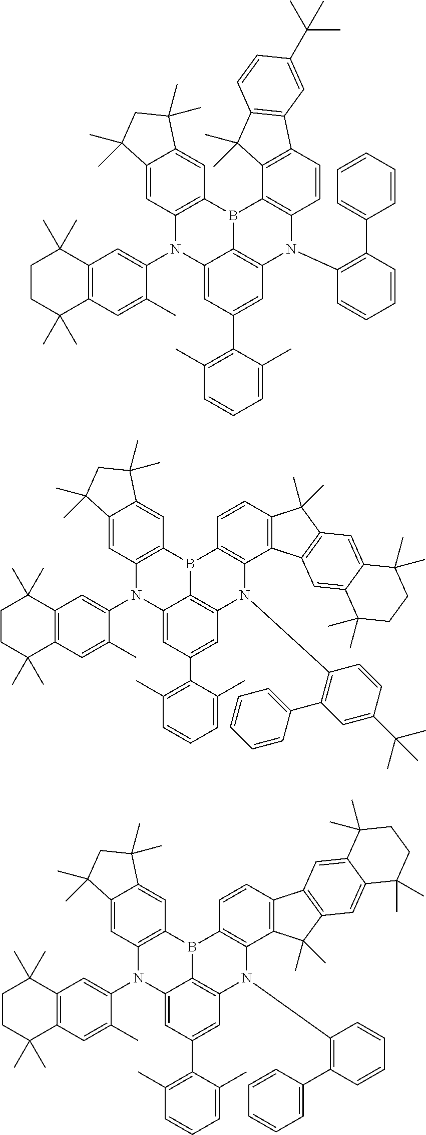 [SMILES: Cc1cc2c(cc1N1c3cc4c(cc3B3c5c1cc(-c1c(C)cccc1C)cc5N(c1ccccc1-c1ccccc1)c1ccc5c(c13)C(C)(C)c1ccc(C(C)(C)C)cc1-5)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(-c7c(C)cccc7C)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(-c7c(C)cccc7C)cc1c53)C(C)(C)c1cc3c(cc1-6)C(C)(C)CCC3(C)C)C(C)(C)CC4(C)C)C(C)(C)CCC2(C)C]

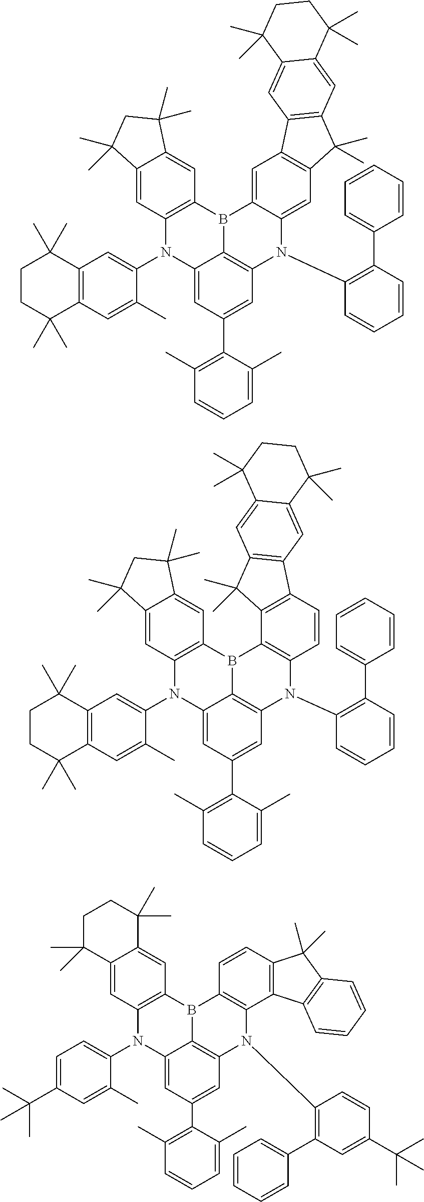

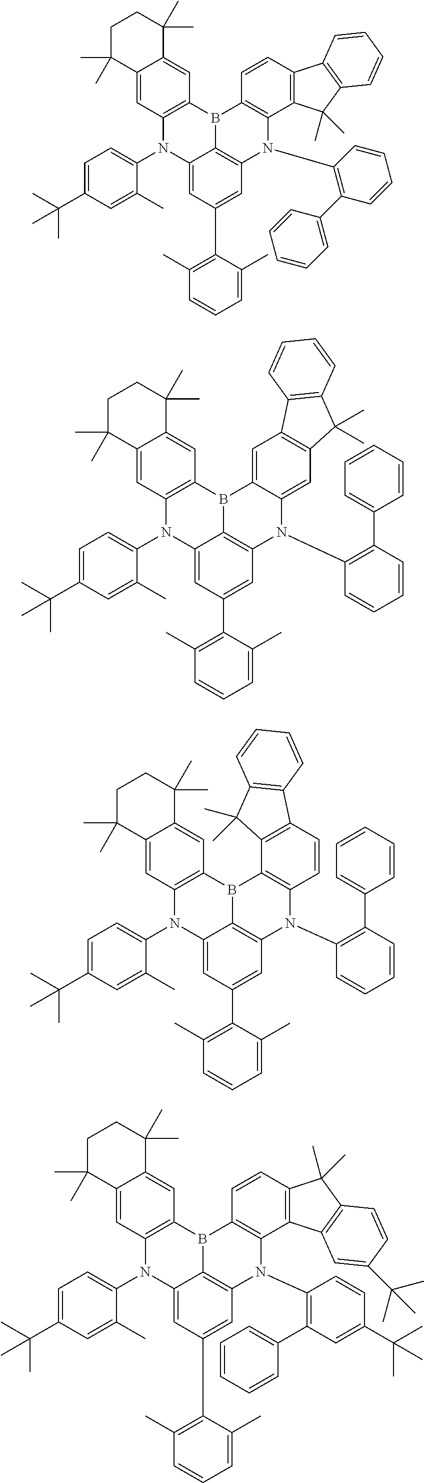

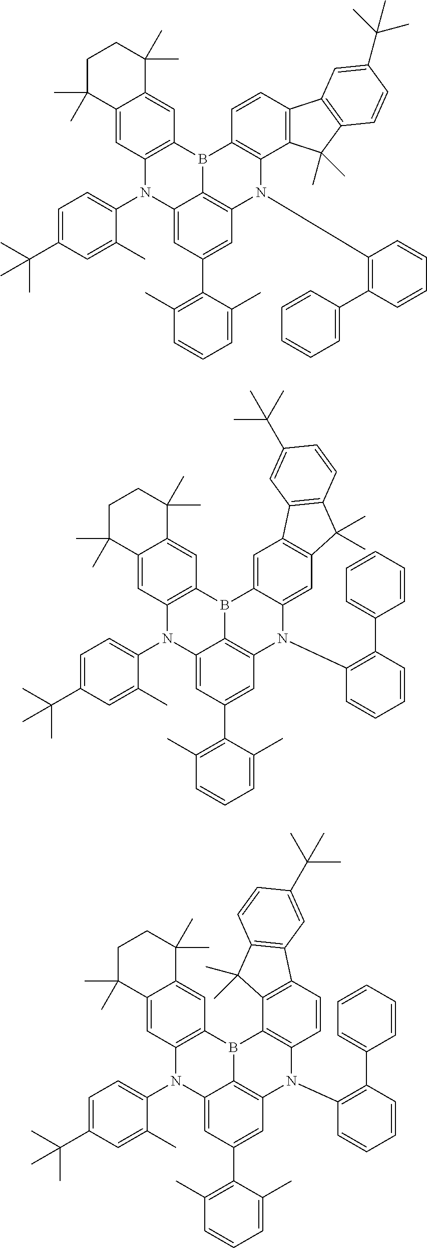

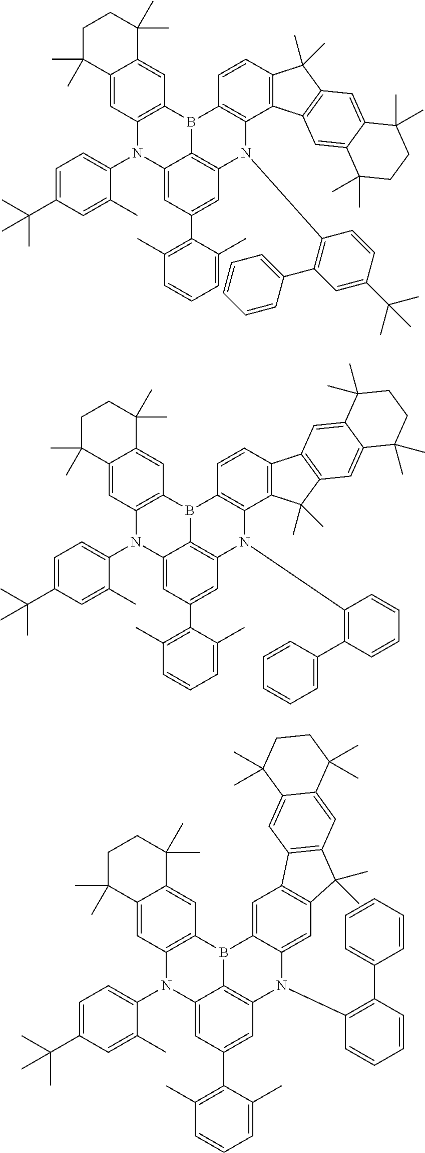

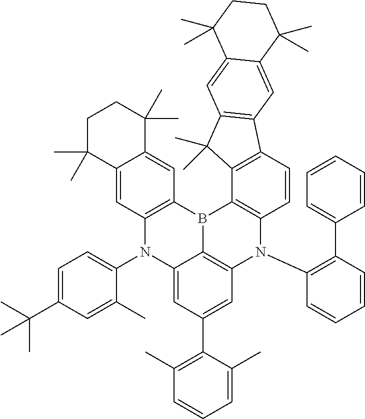 [SMILES: Cc1cc(C(C)(C)C)ccc1N1c2cc3c(cc2B2c4c1cc(-c1c(C)cccc1C)cc4N(c1ccccc1-c1ccccc1)c1ccc4c(c12)C(C)(C)c1cc2c(cc1-4)C(C)(C)CCC2(C)C)C(C)(C)CCC3(C)C]

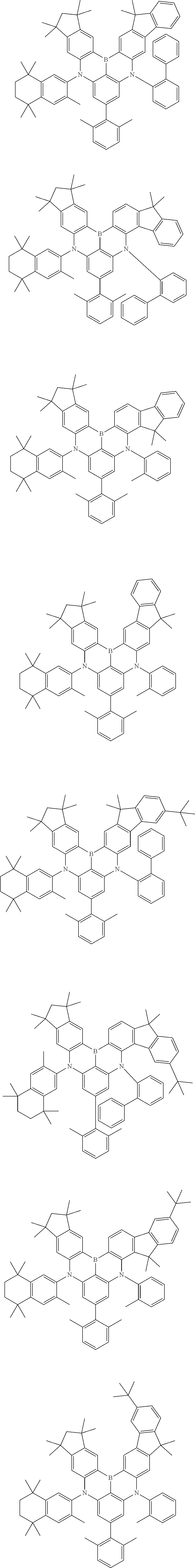

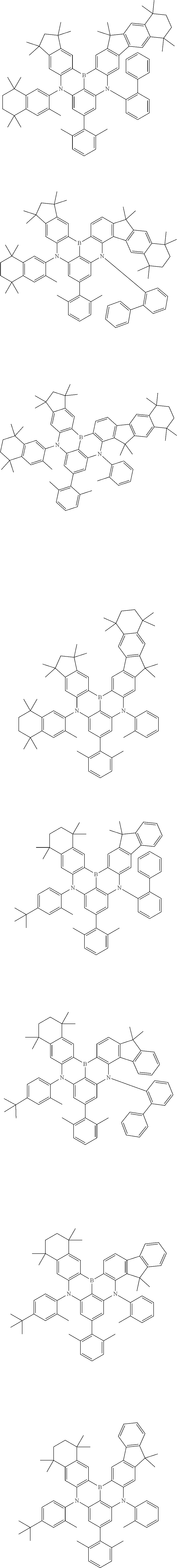

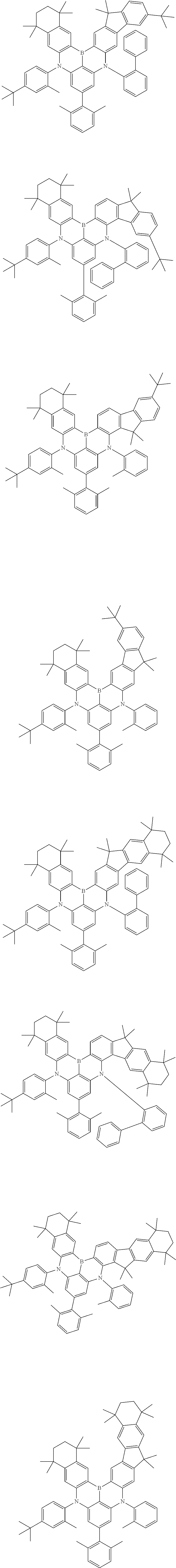

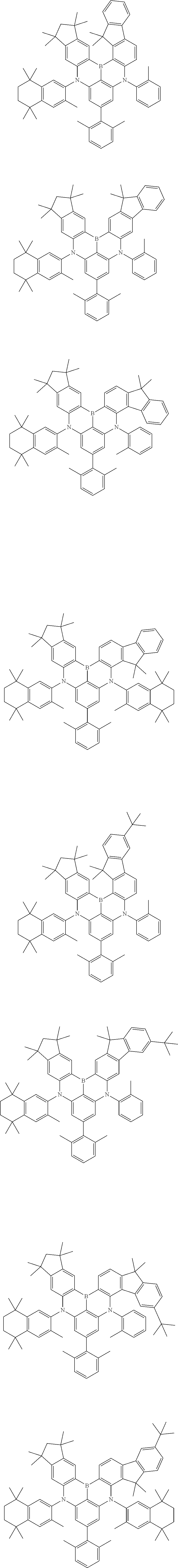

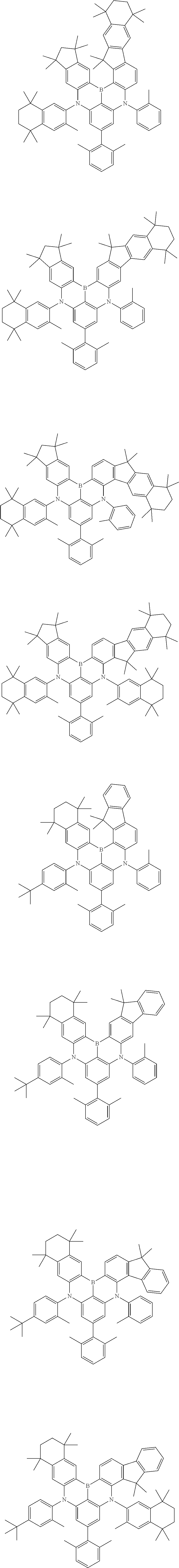

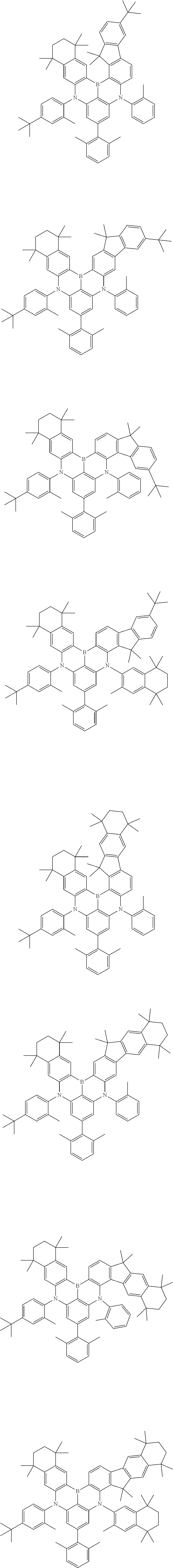

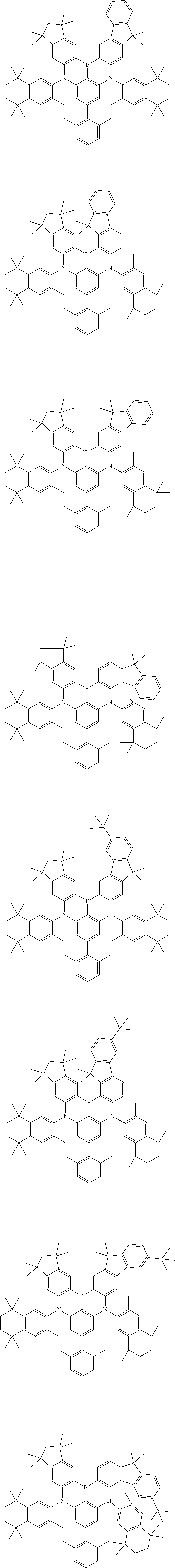

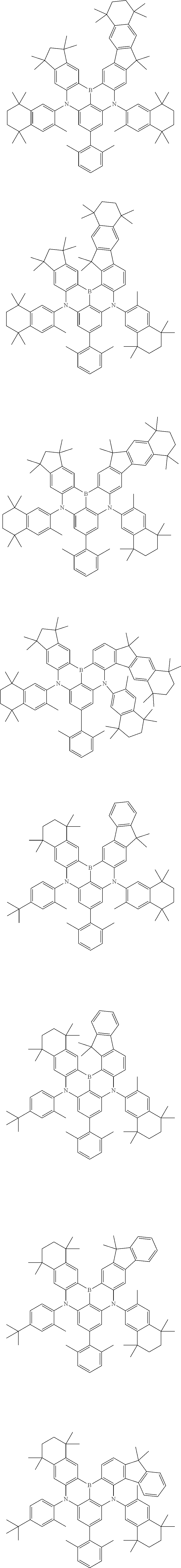

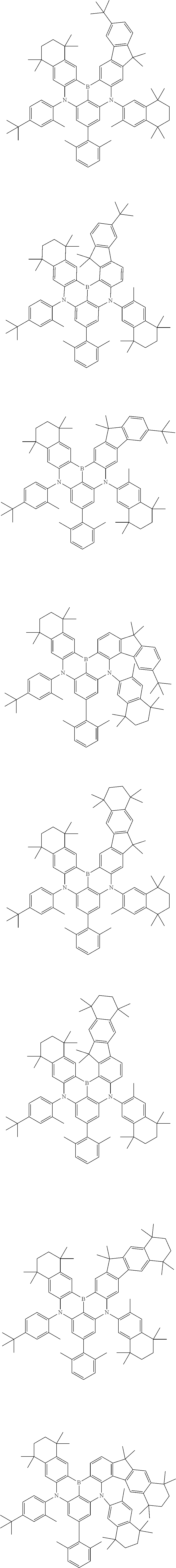

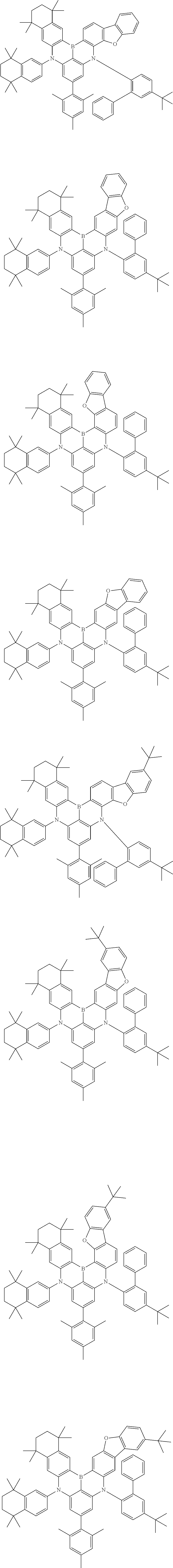

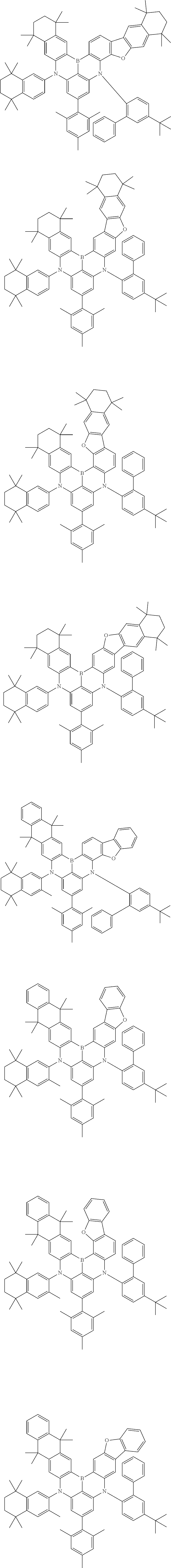

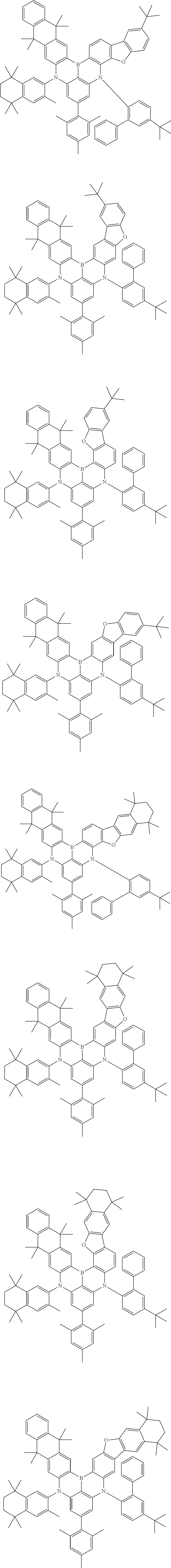

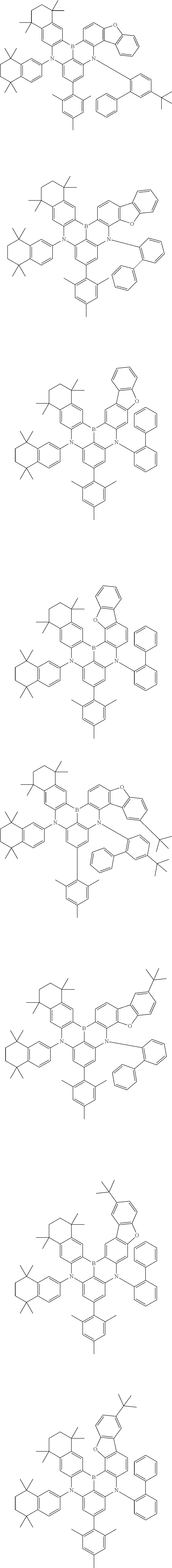

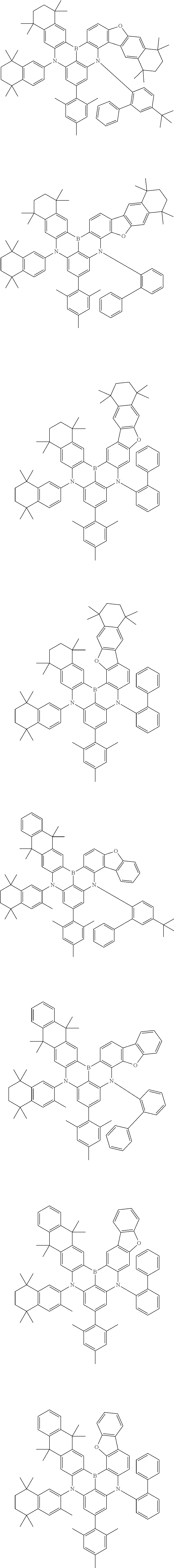

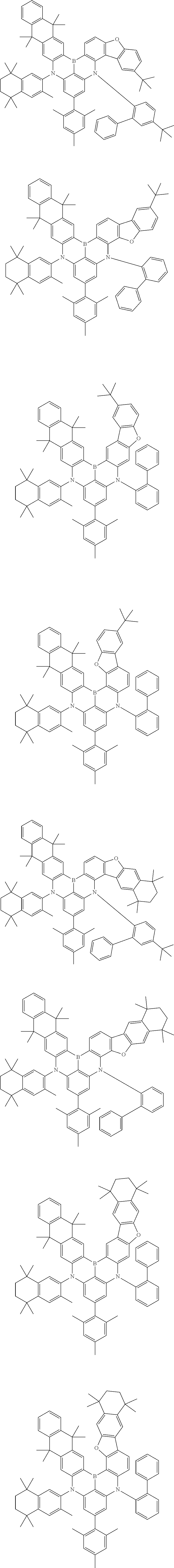

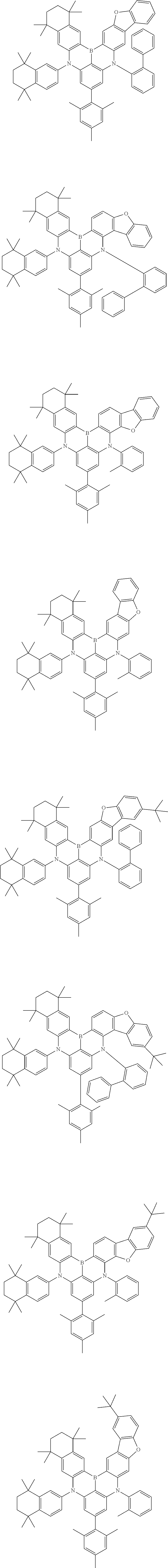

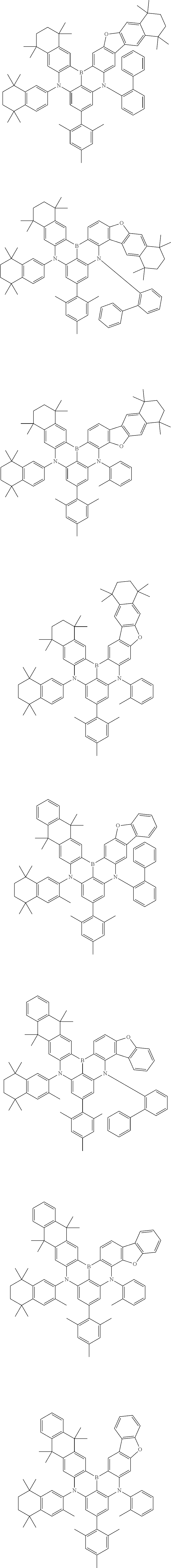

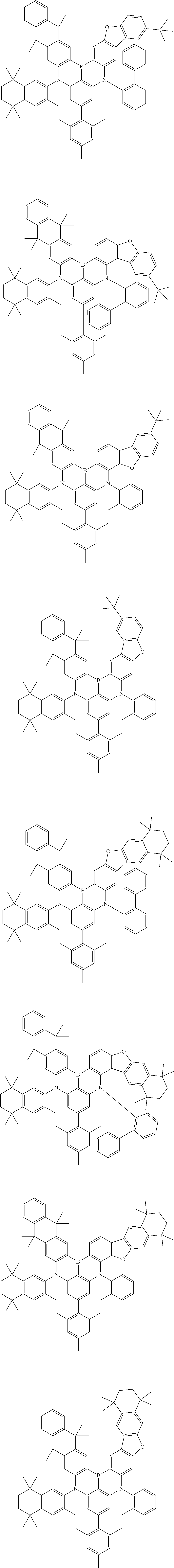

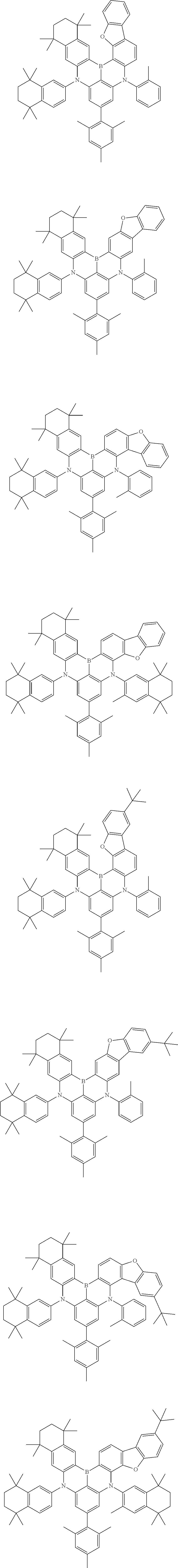

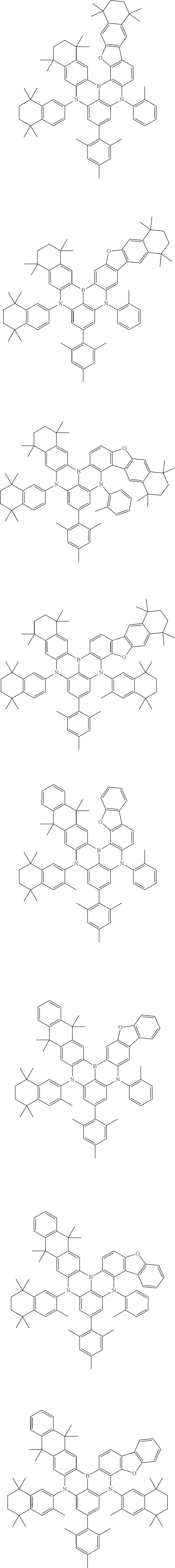

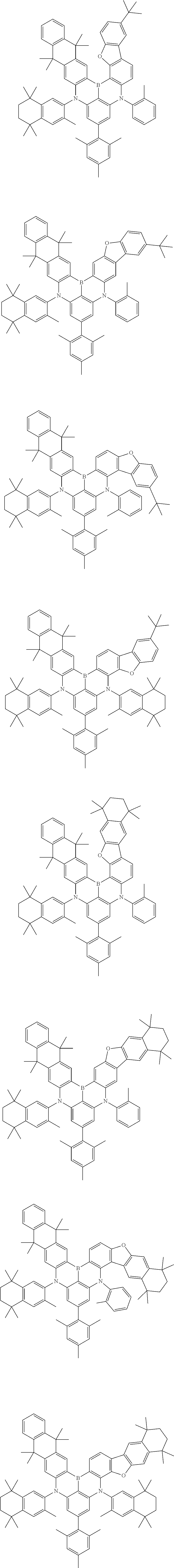

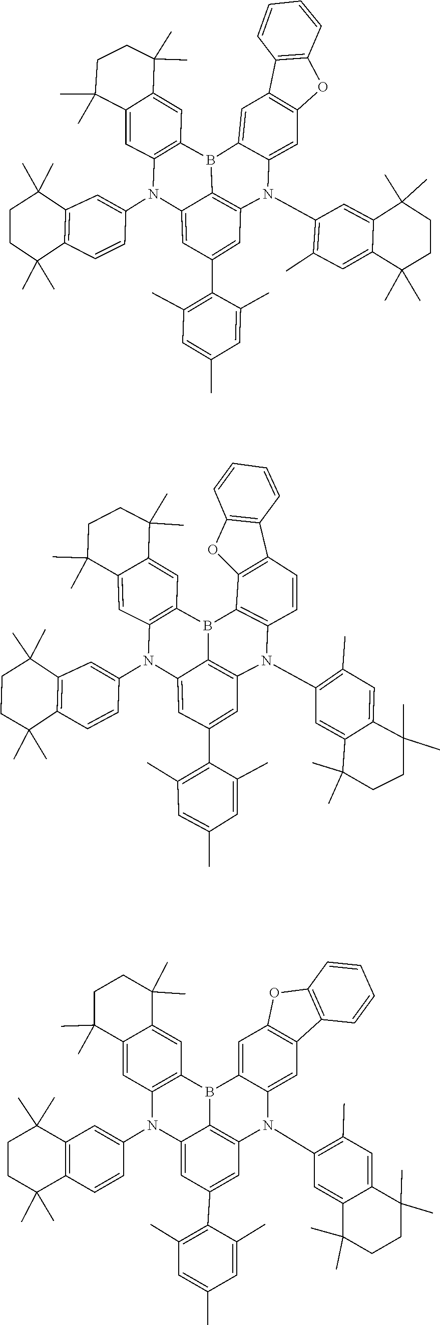 [SMILES: Cc1cc(C)c(-c2cc3c4c(c2)N(c2cc5c(cc2C)C(C)(C)CCC5(C)C)c2cc5oc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccc5c(oc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2ccccc25)c(C)c1]

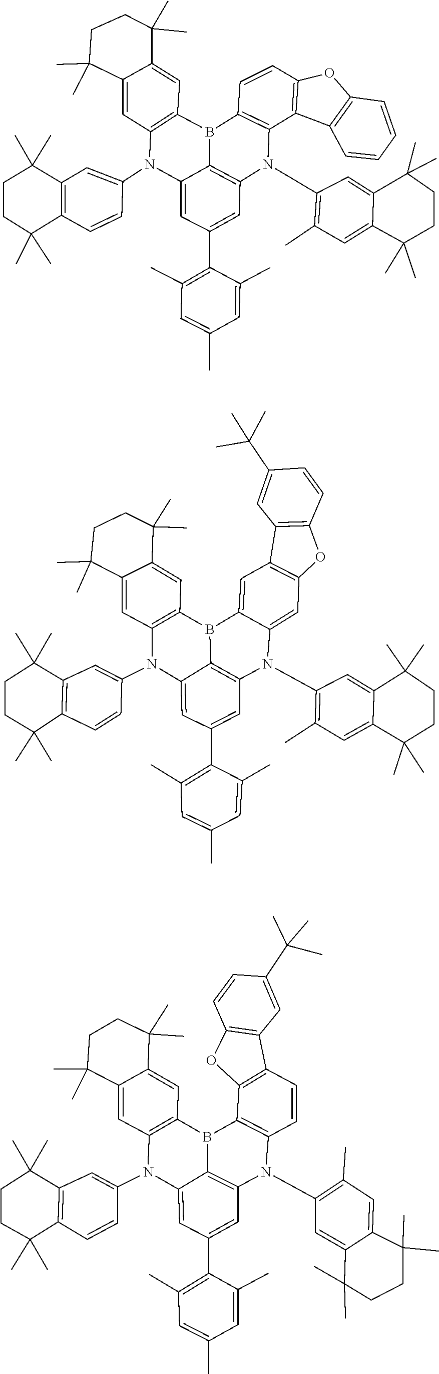 [SMILES: Cc1cc(C)c(-c2cc3c4c(c2)N(c2cc5c(cc2C)C(C)(C)CCC5(C)C)c2c(ccc5oc6ccccc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5oc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccc5c(oc6ccc(C(C)(C)C)cc65)c2B4c2cc4c(cc2N3c2ccc3c(c2)C(C)(C)CCC3(C)C)C(C)(C)CCC4(C)C)c(C)c1]

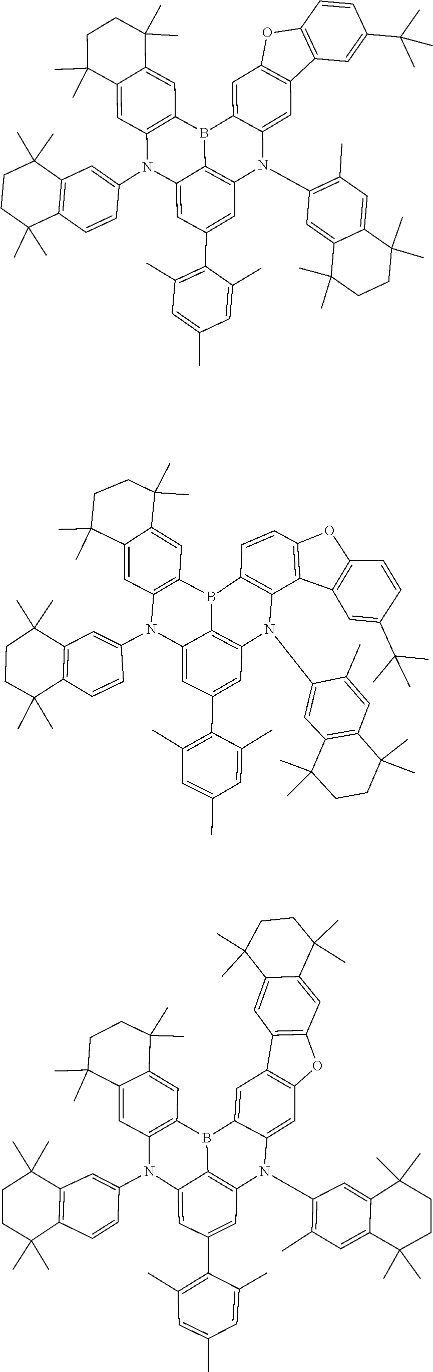 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

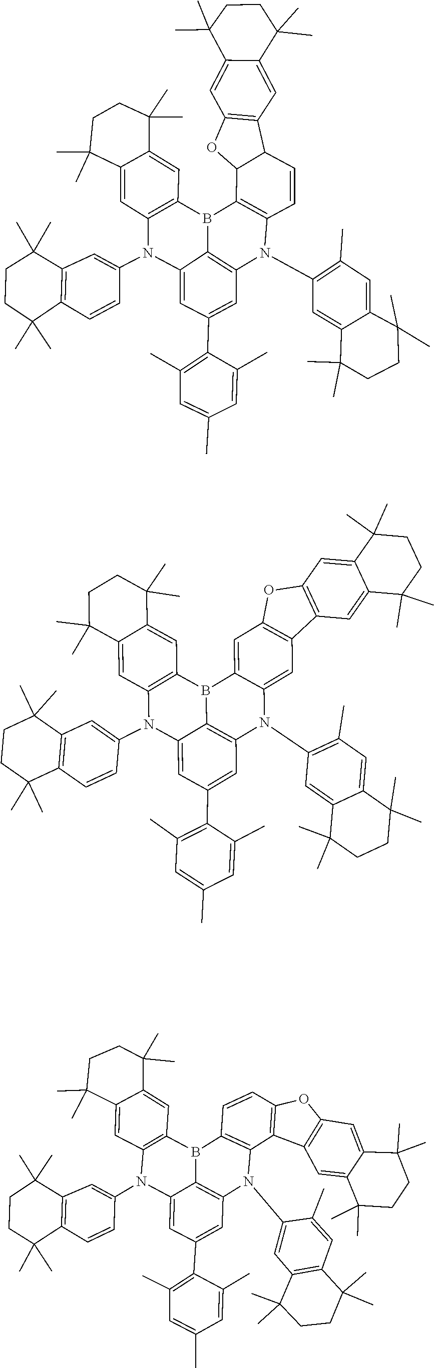 [SMILES: Cc1cc(C)c(-c2cc3c4c(c2)N(c2ccc5c(c2)C(C)(C)CCC5(C)C)c2cc5c(cc2B4C2=C(C=CC4c6cc7c(cc6OC24)C(C)(C)CCC7(C)C)N3c2cc3c(cc2C)C(C)(C)CCC3(C)C)C(C)(C)CCC5(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

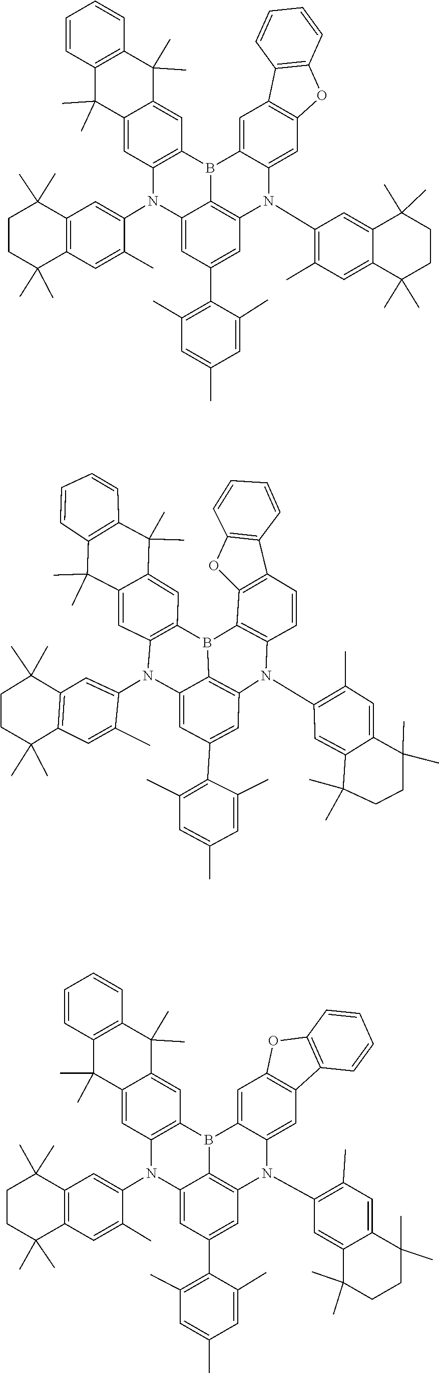 [SMILES: Cc1cc(C)c(-c2cc3c4c(c2)N(c2cc5c(cc2C)C(C)(C)CCC5(C)C)c2cc5oc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)oc2ccccc25)c(C)c1]

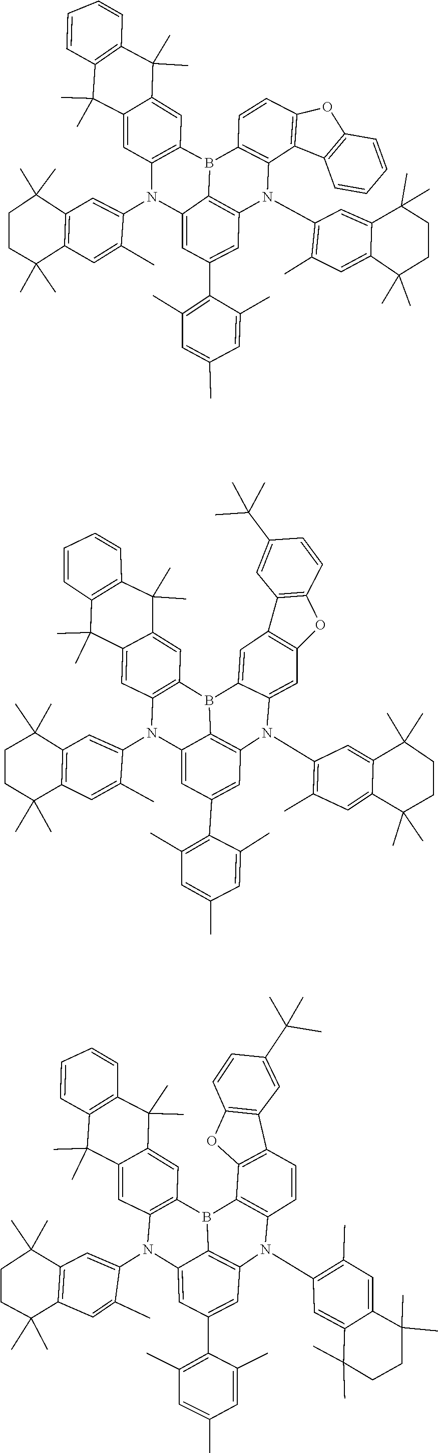 [SMILES: Cc1cc(C)c(-c2cc3c4c(c2)N(c2cc5c(cc2C)C(C)(C)CCC5(C)C)c2c(ccc5oc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1]

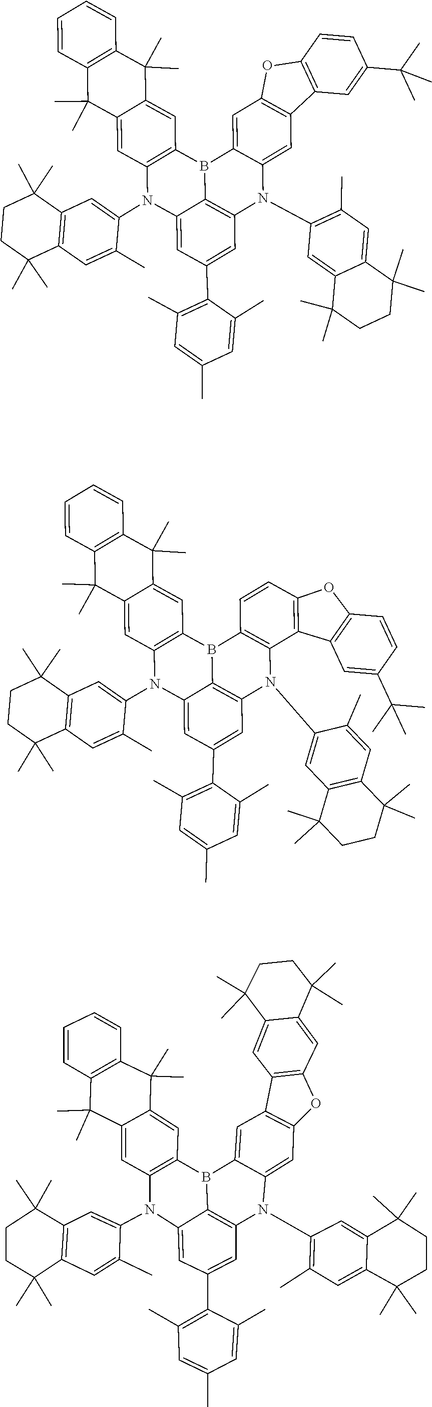 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1]

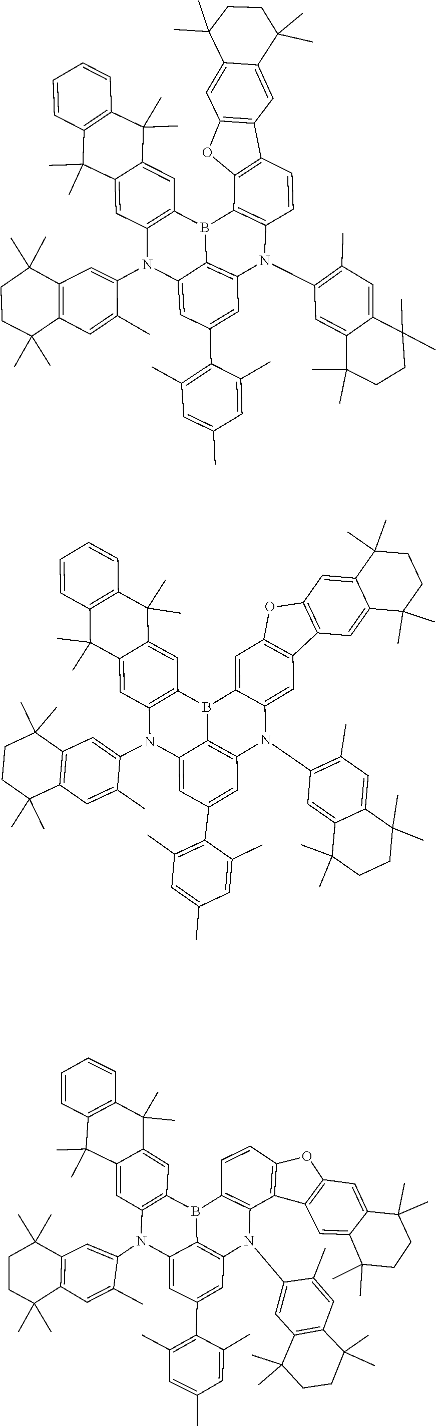 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1]

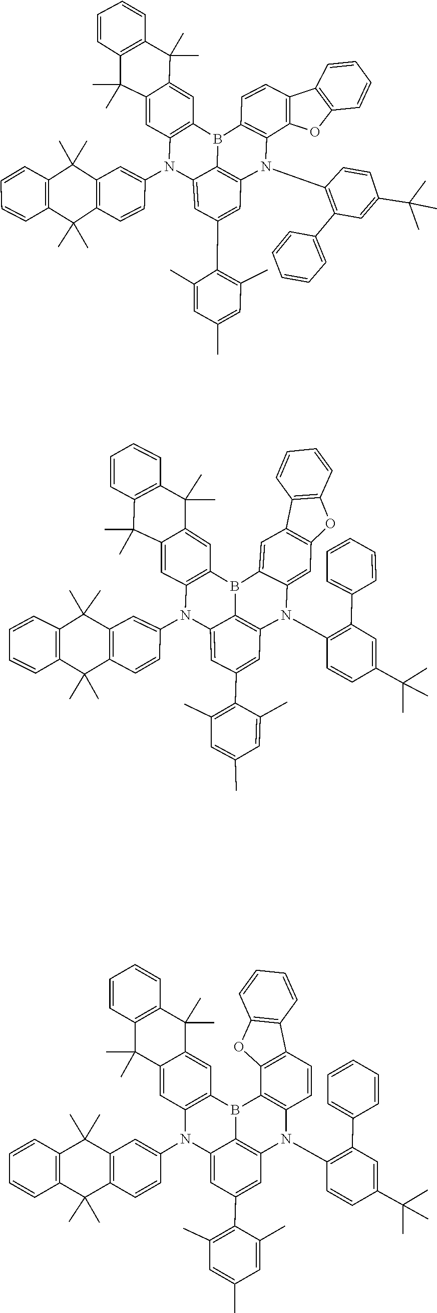 [SMILES: Cc1cc(C)c(-c2cc3c4c(c2)N(c2ccc(C(C)(C)C)cc2-c2ccccc2)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1]

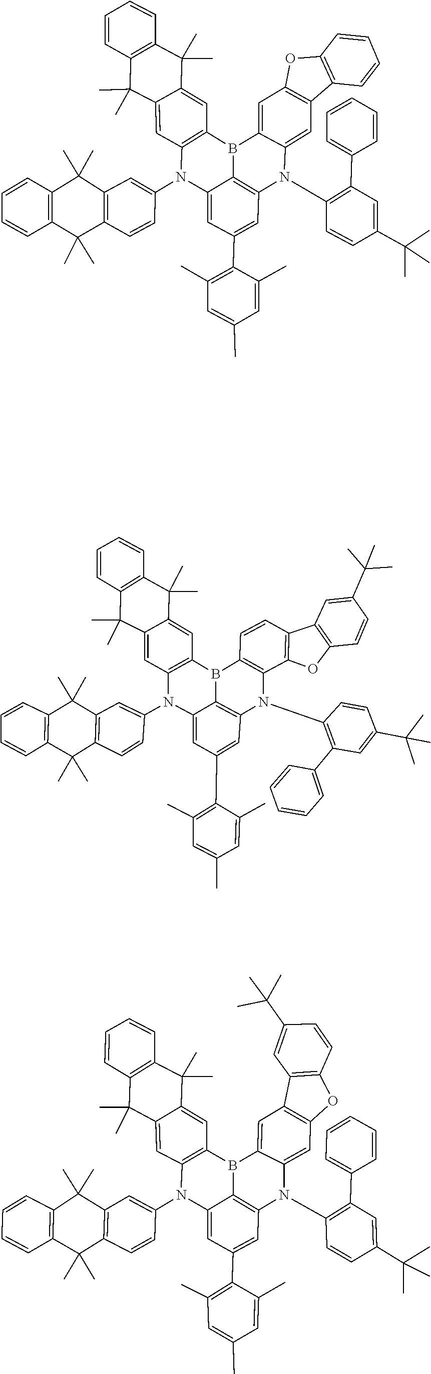 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1 ; Cc1cc(C)c(-c2cc3c4c(c2)N(c2ccc(C(C)(C)C)cc2-c2ccccc2)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1]

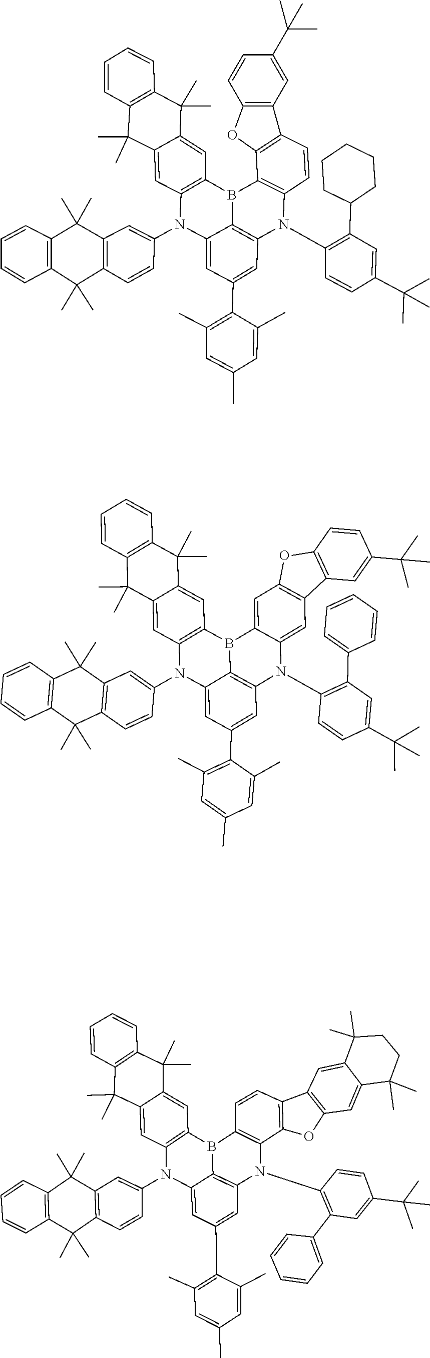 [SMILES: Cc1cc(C)c(-c2cc3c4c(c2)N(c2ccc(C(C)(C)C)cc2C2CCCCC2)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

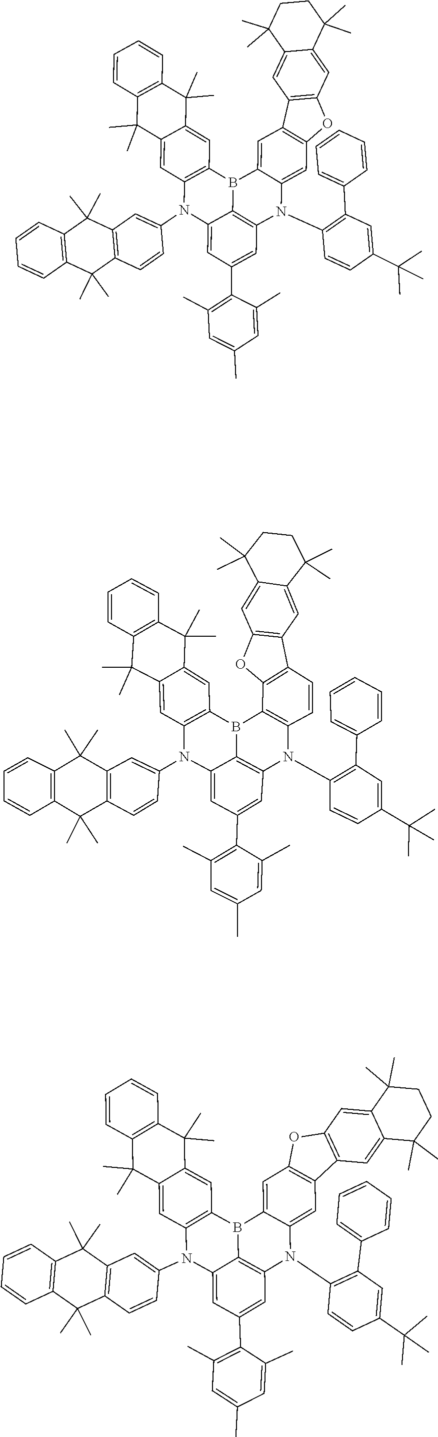

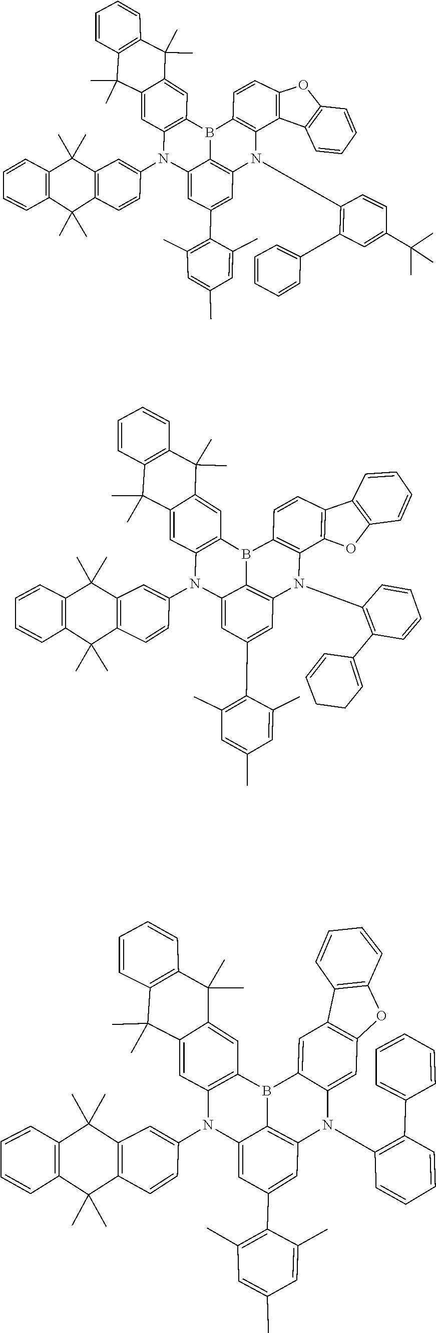 [SMILES: Cc1cc(C)c(-c2cc3c4c(c2)N(c2ccc(C(C)(C)C)cc2-c2ccccc2)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C2=CCCC=C2)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1]

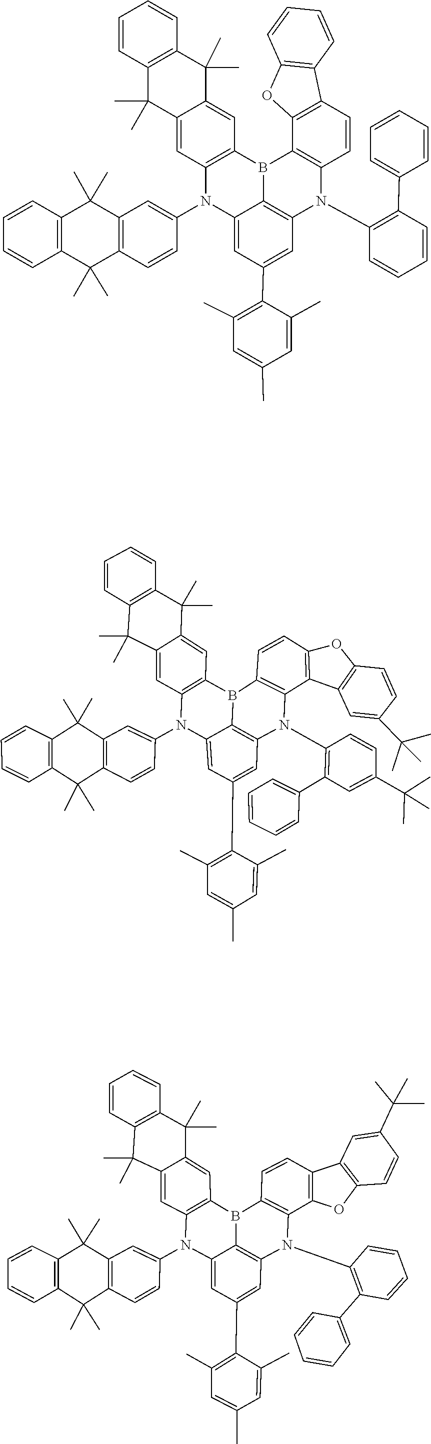 [SMILES: Cc1cc(C)c(-c2cc3c4c(c2)N(c2ccccc2-c2ccccc2)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1]

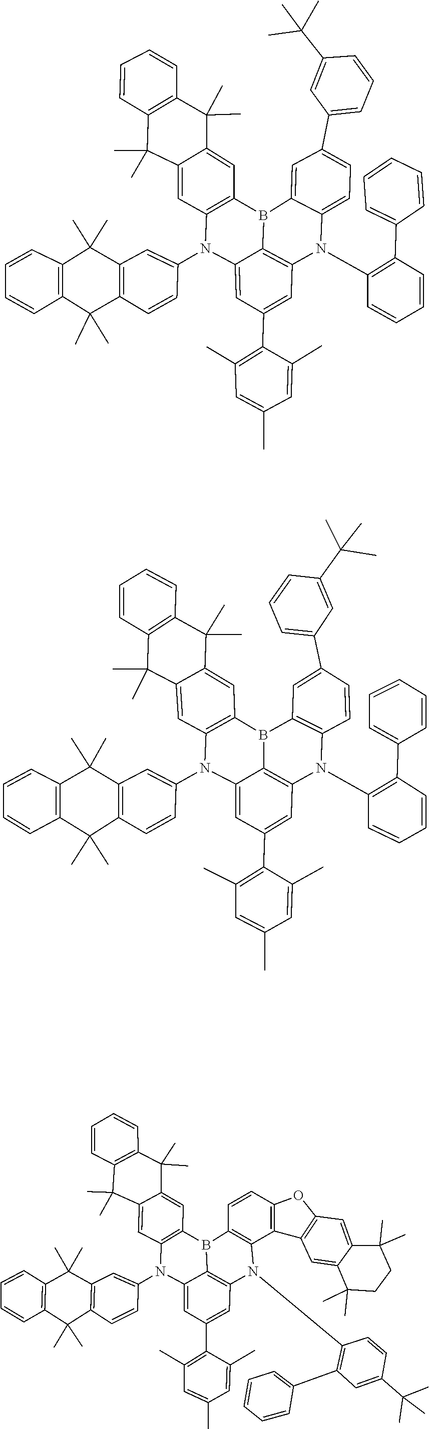 [SMILES: Cc1cc(C)c(-c2cc3c4c(c2)N(c2ccccc2-c2ccccc2)c2ccc(-c5cccc(C(C)(C)C)c5)cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2ccc(-c5cccc(C(C)(C)C)c5)cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1]

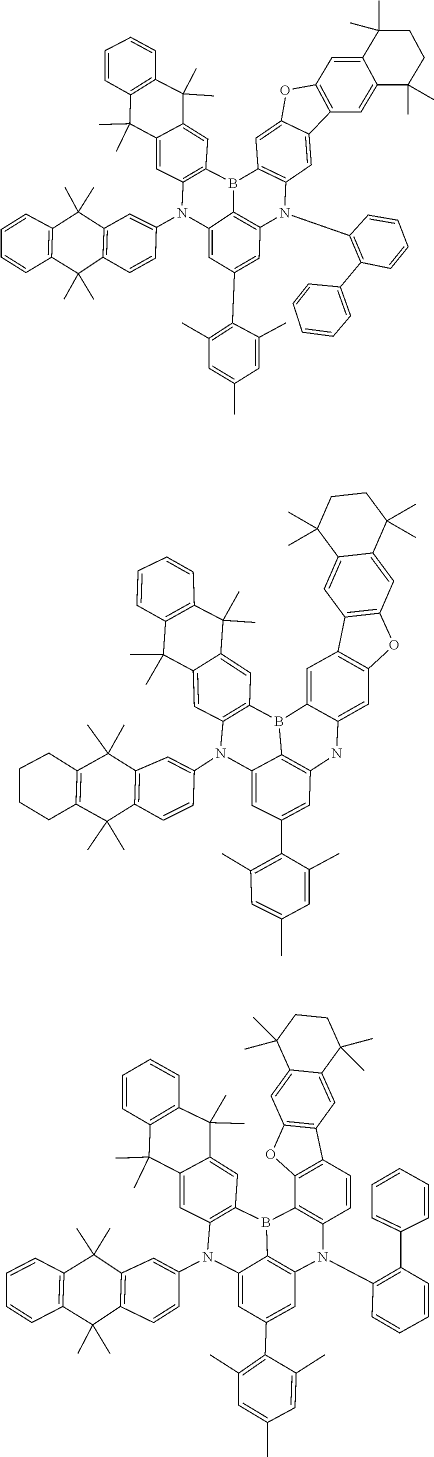 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2cc3c(cc25)C(C)(C)CCC3(C)C)c(C)c1 ; Cc1cc(C)c(-c2cc3c4c(c2)N(c2ccc5c(c2)C(C)(C)C2=C(CCCC2)C5(C)C)c2cc5c(cc2B4c2cc4c(cc2N3)oc2cc3c(cc24)C(C)(C)CCC3(C)C)C(C)(C)c2ccccc2C5(C)C)c(C)c1 ; Cc1cc(C)c(-c2cc3c4c(c2)N(c2ccccc2-c2ccccc2)c2ccc5c(oc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

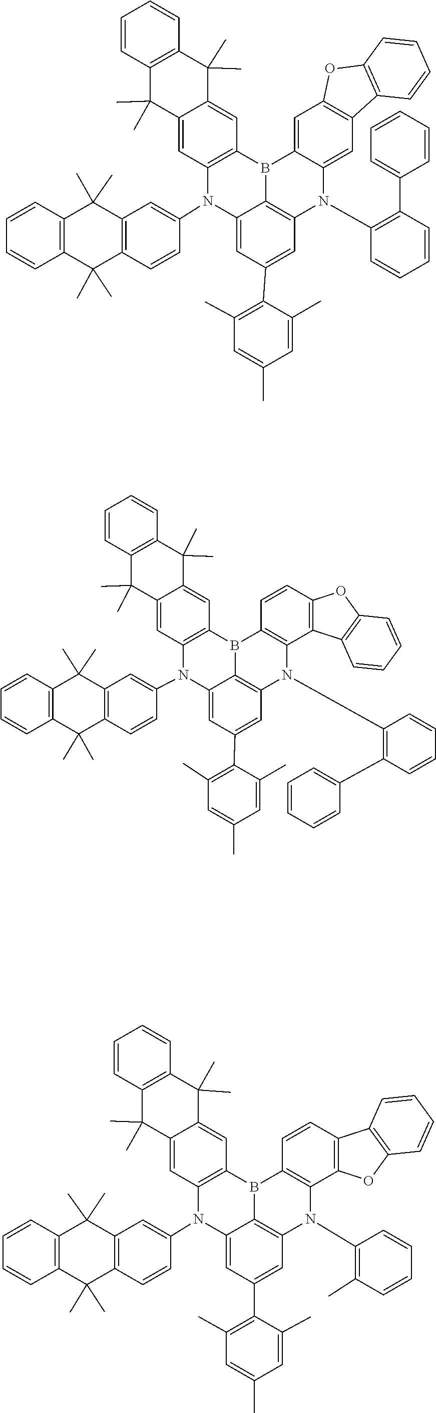 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1]

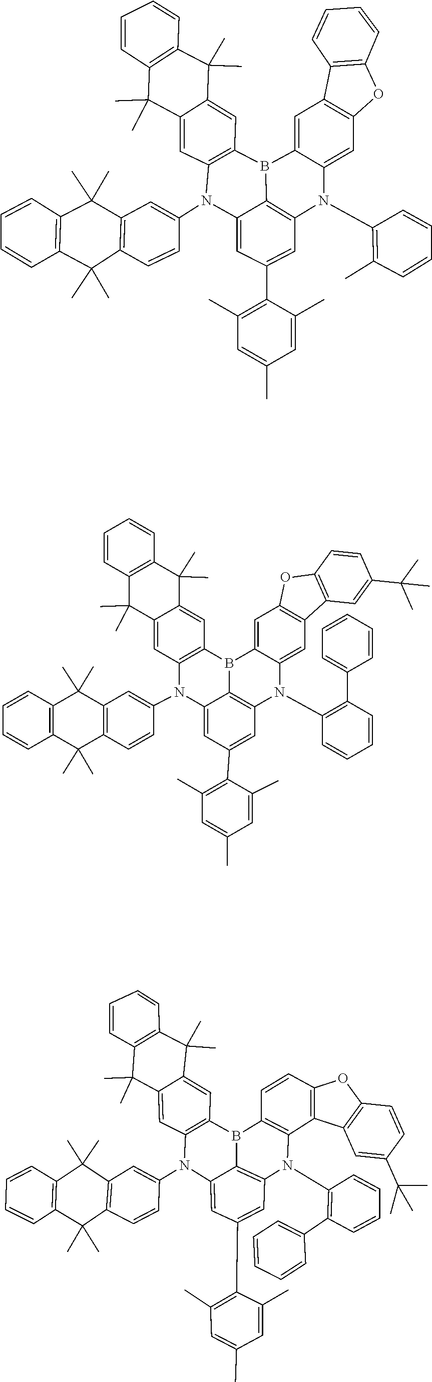 [SMILES: Cc1cc(C)c(-c2cc3c4c(c2)N(c2ccccc2C)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1 ; Cc1cc(C)c(-c2cc3c4c(c2)N(c2ccccc2-c2ccccc2)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1]

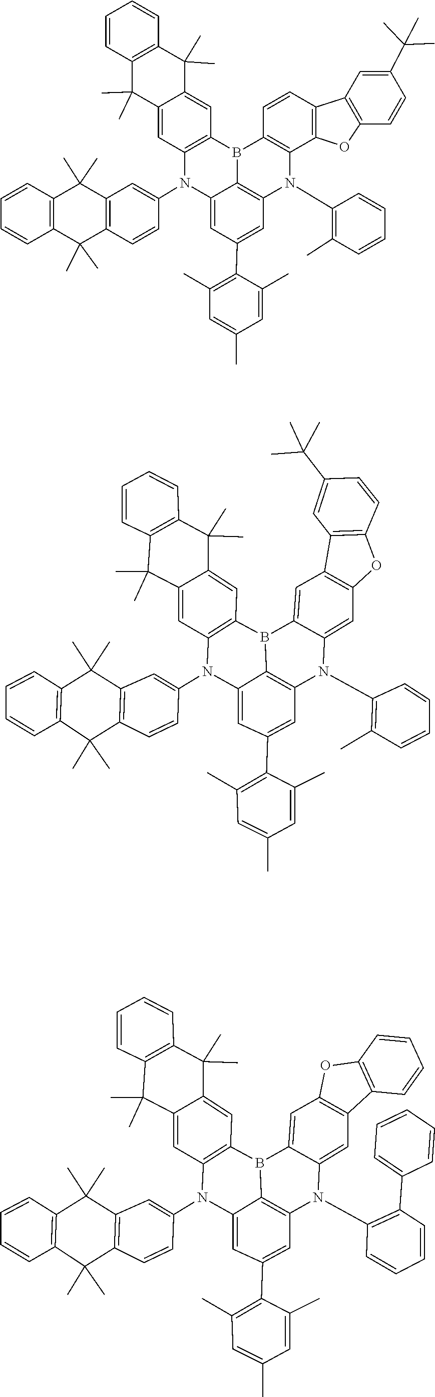 [SMILES: Cc1cc(C)c(-c2cc3c4c(c2)N(c2ccccc2C)c2c(ccc5c2oc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1]

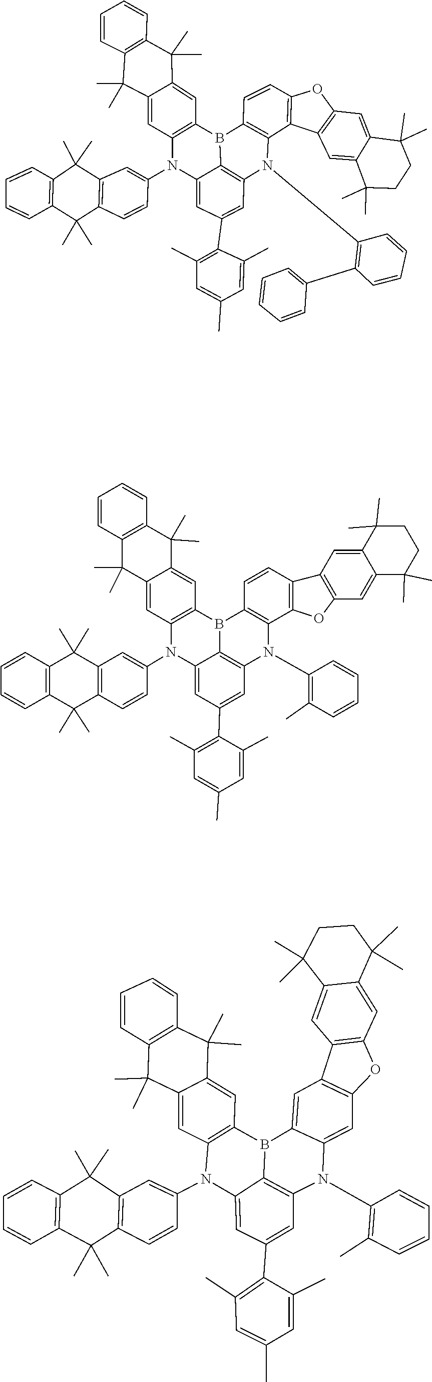 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5oc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

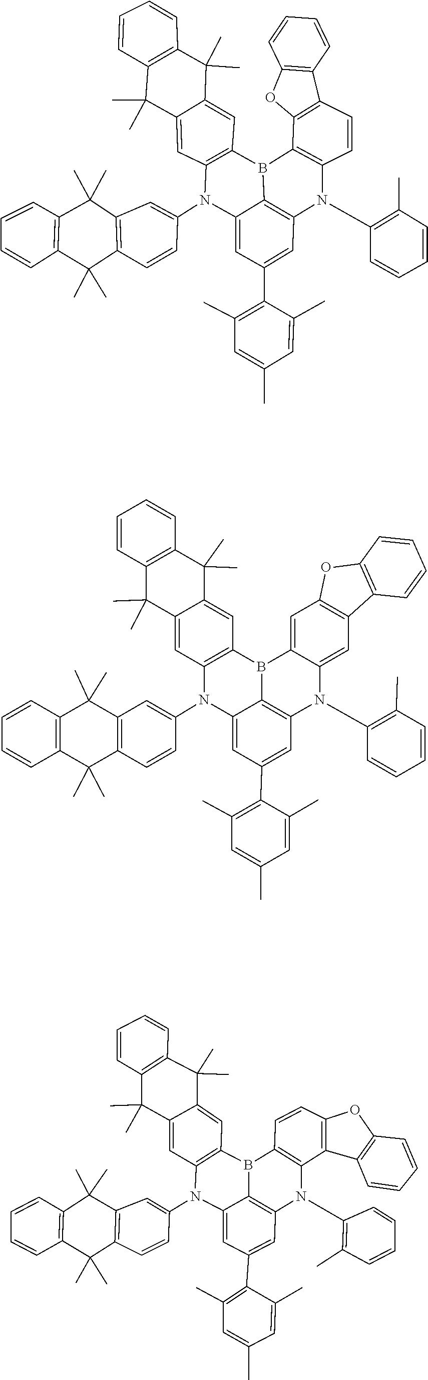 [SMILES: Cc1cc(C)c(-c2cc3c4c(c2)N(c2ccccc2C)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1]

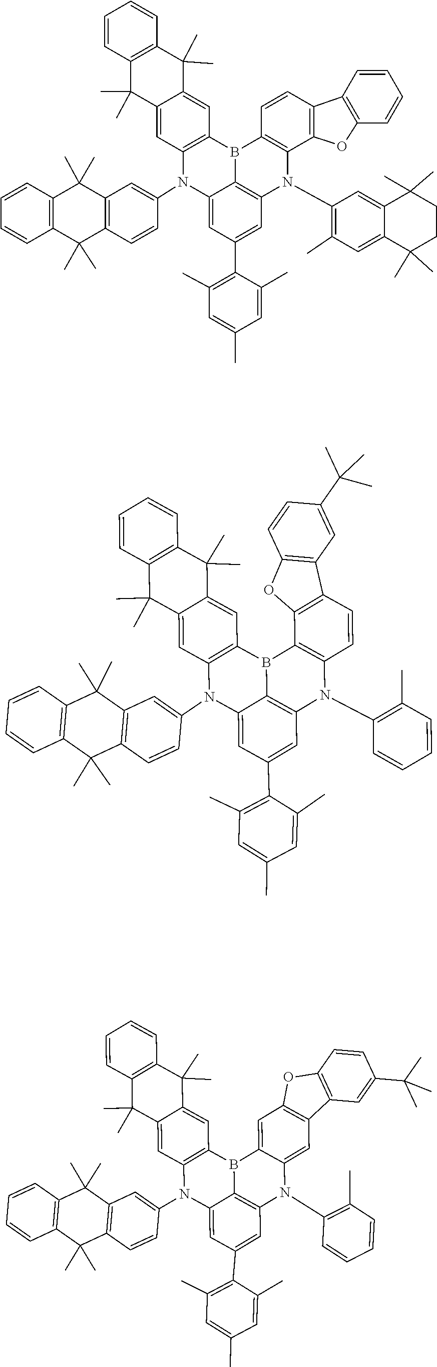 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1]

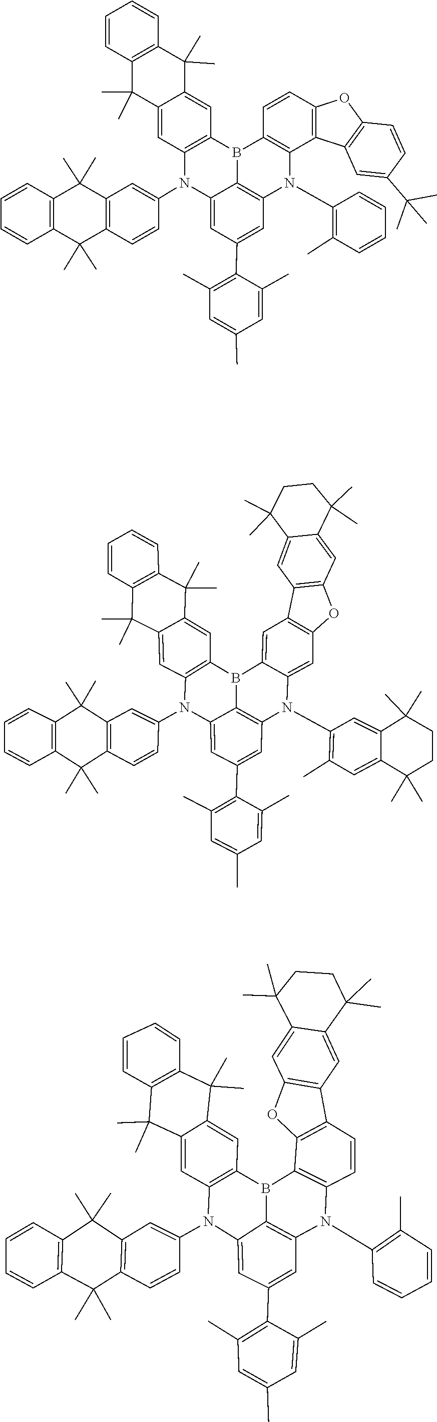 [SMILES: Cc1cc(C)c(-c2cc3c4c(c2)N(c2ccccc2C)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1 ; Cc1cc(C)c(-c2cc3c4c(c2)N(c2ccccc2C)c2ccc5c(oc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

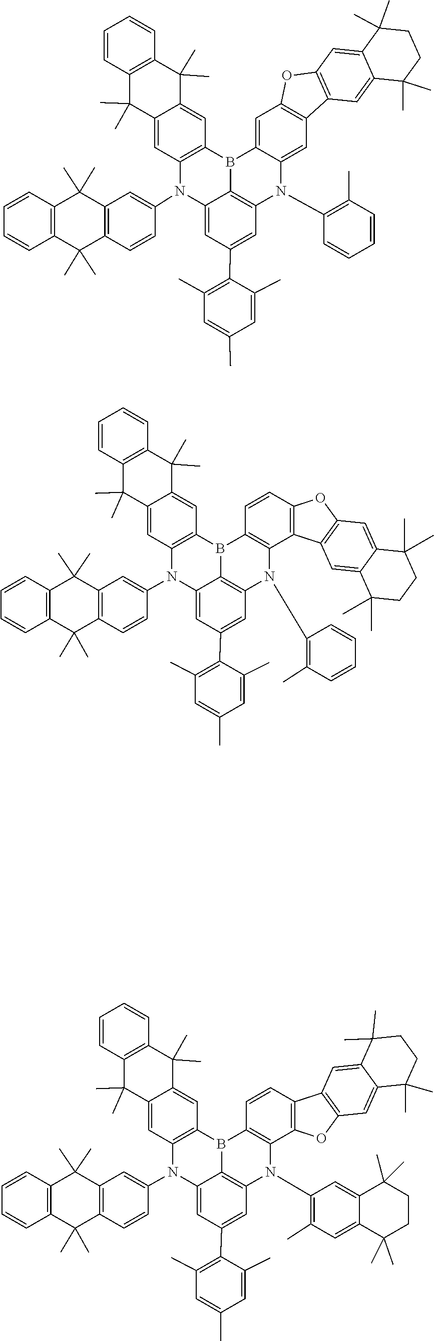 [SMILES: Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

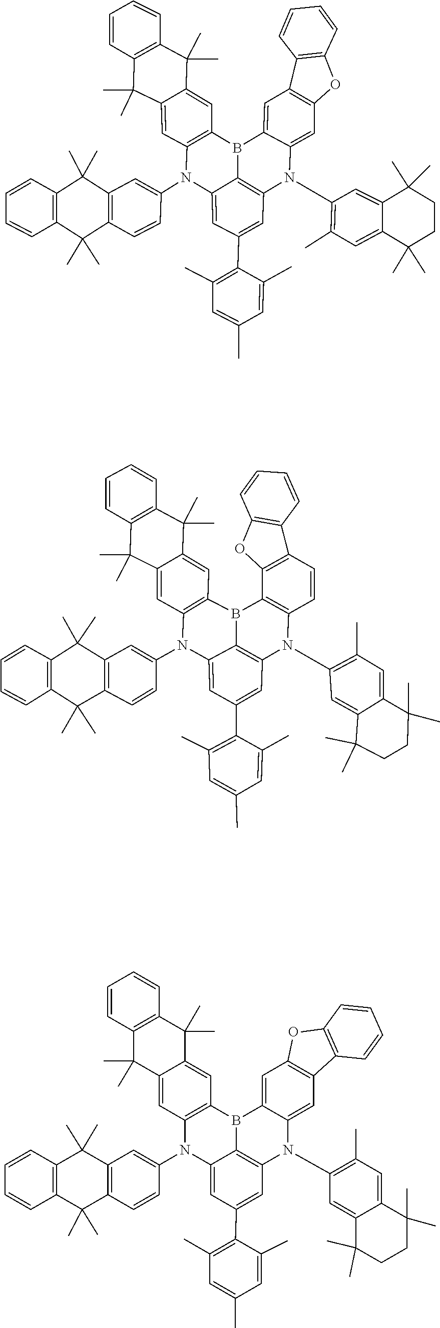 [SMILES: Cc1cc(C)c(-c2cc3c4c(c2)N(c2cc5c(cc2C)C(C)(C)CCC5(C)C)c2cc5oc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)oc2ccccc25)c(C)c1]

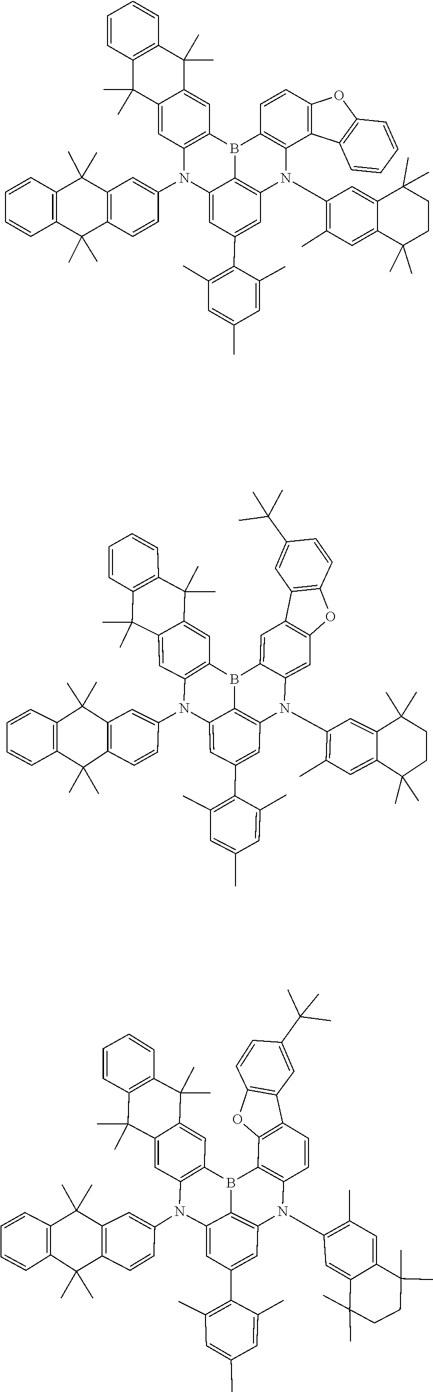 [SMILES: Cc1cc(C)c(-c2cc3c4c(c2)N(c2cc5c(cc2C)C(C)(C)CCC5(C)C)c2c(ccc5oc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(oc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1]

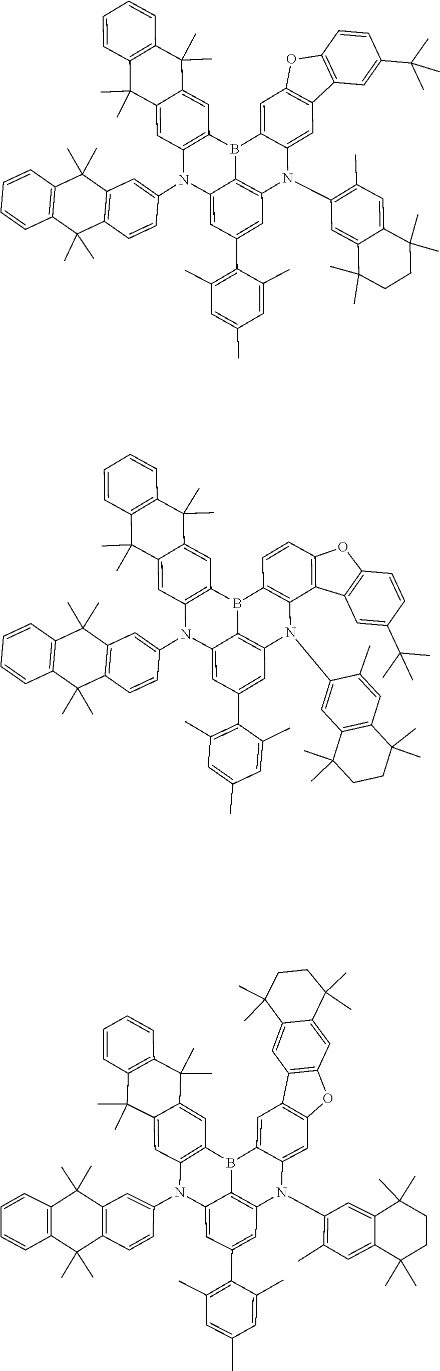 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

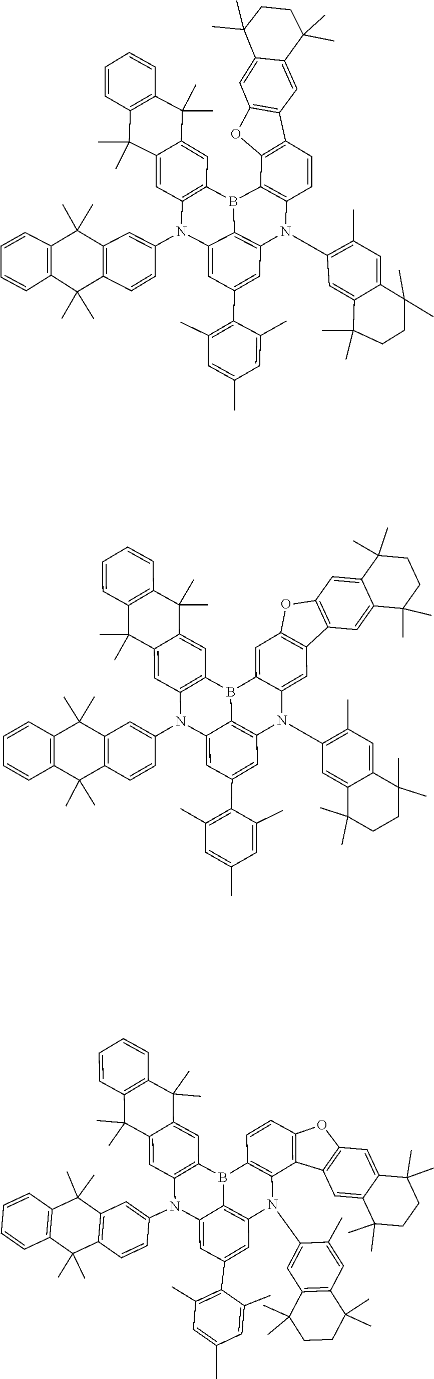

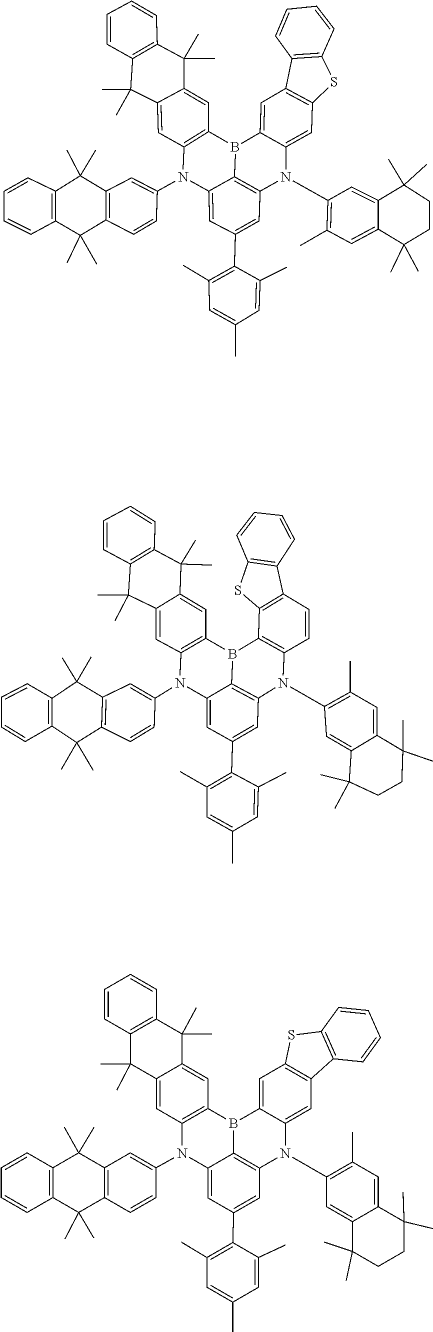 [SMILES: Cc1cc(C)c(-c2cc3c4c(c2)N(c2cc5c(cc2C)C(C)(C)CCC5(C)C)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1]

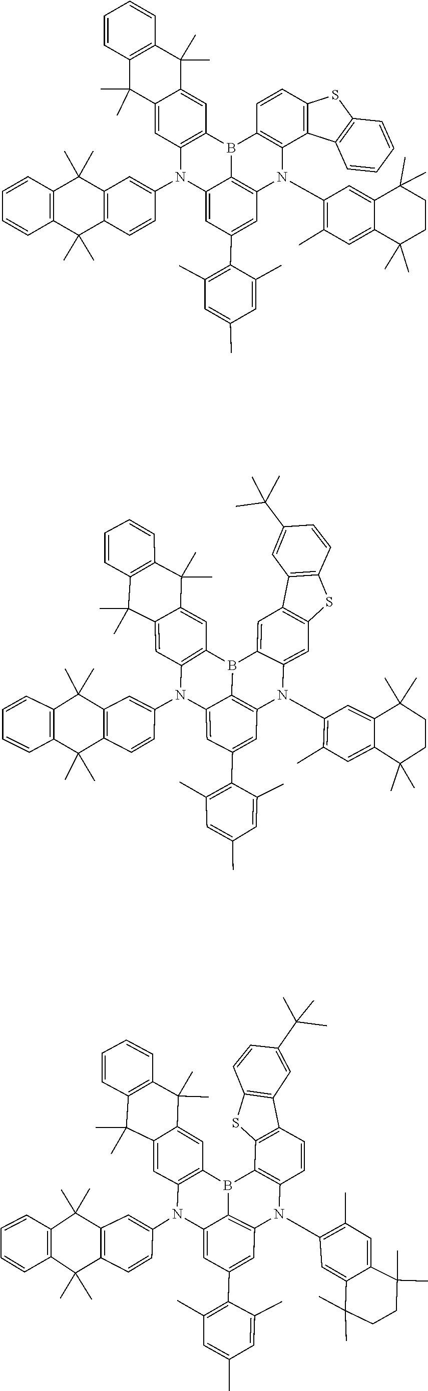 [SMILES: Cc1cc(C)c(-c2cc3c4c(c2)N(c2cc5c(cc2C)C(C)(C)CCC5(C)C)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1]

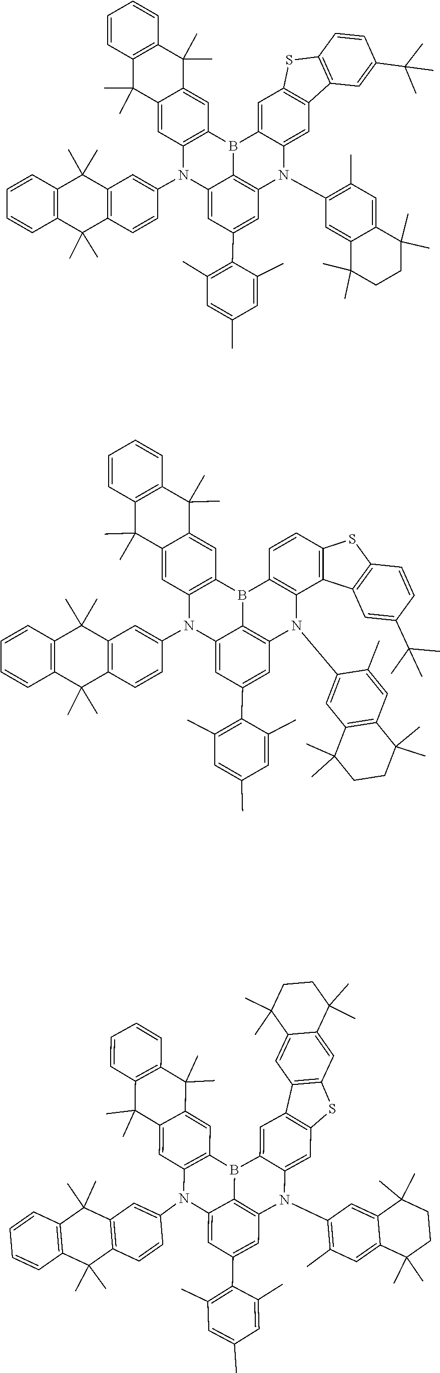 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5sc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

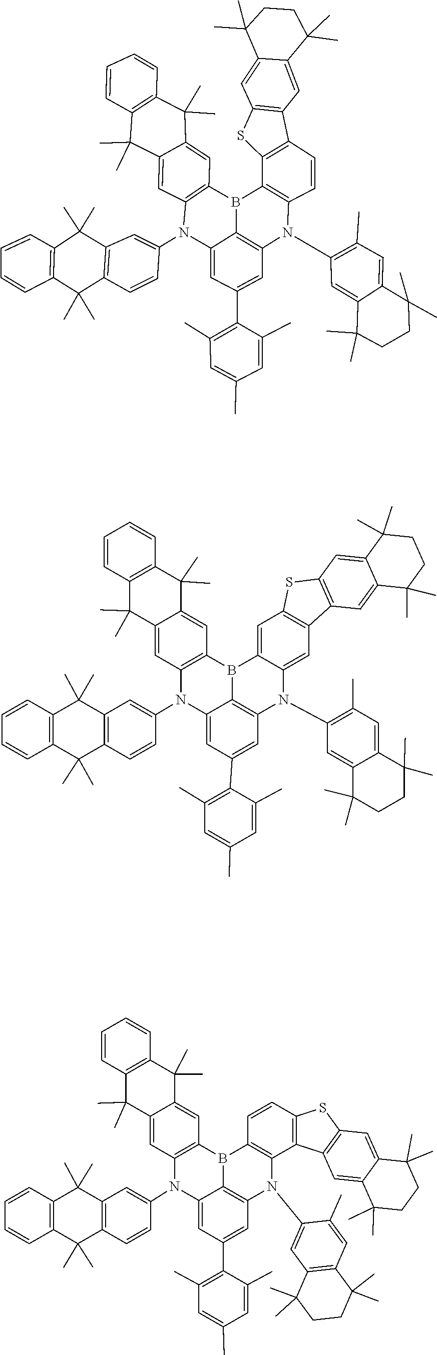

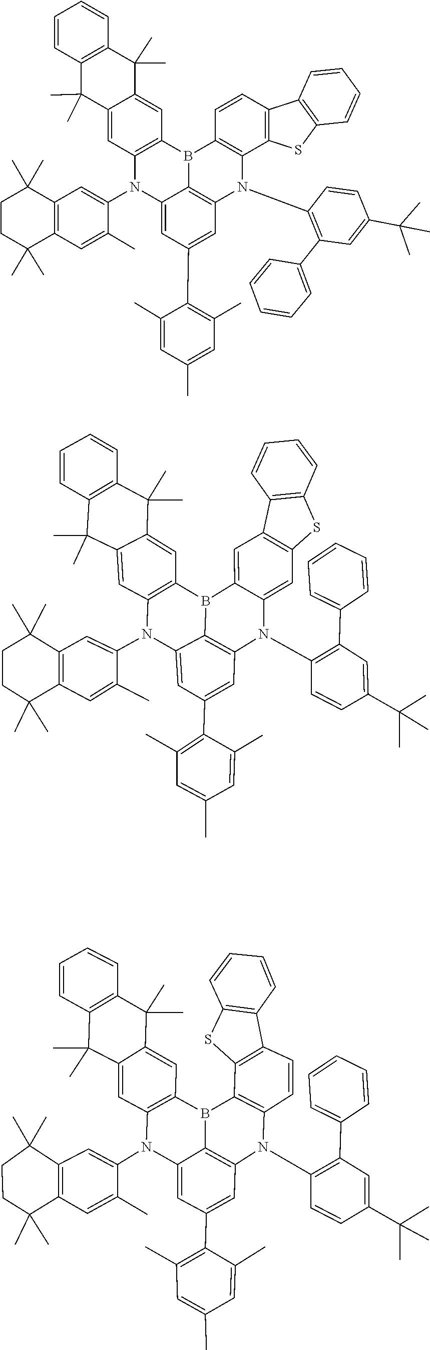 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2cc3c(cc2C)C(C)(C)CCC3(C)C)C(C)(C)c2ccccc2C4(C)C)c(C)c1]

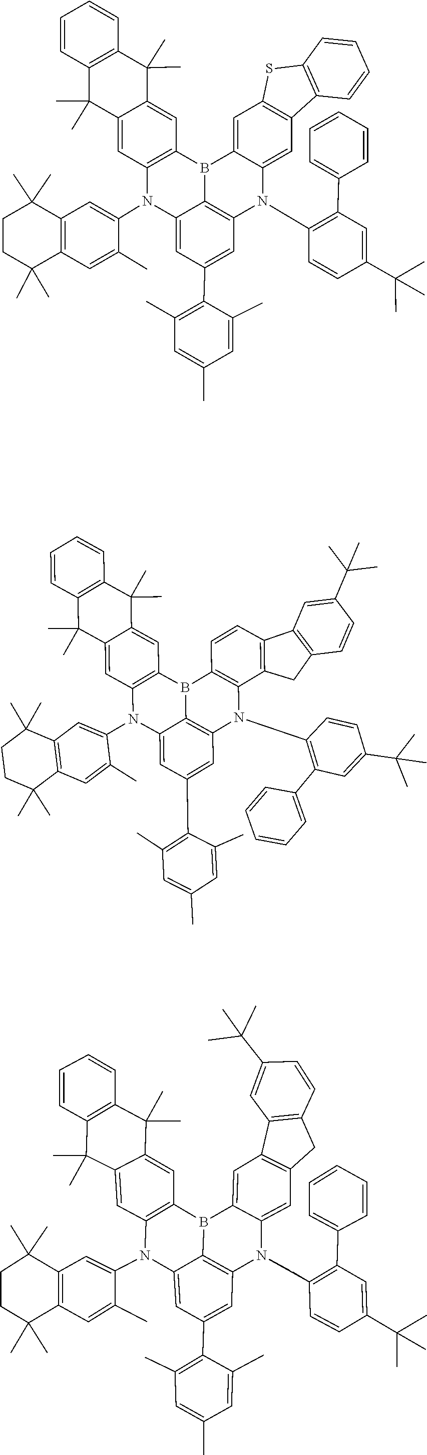

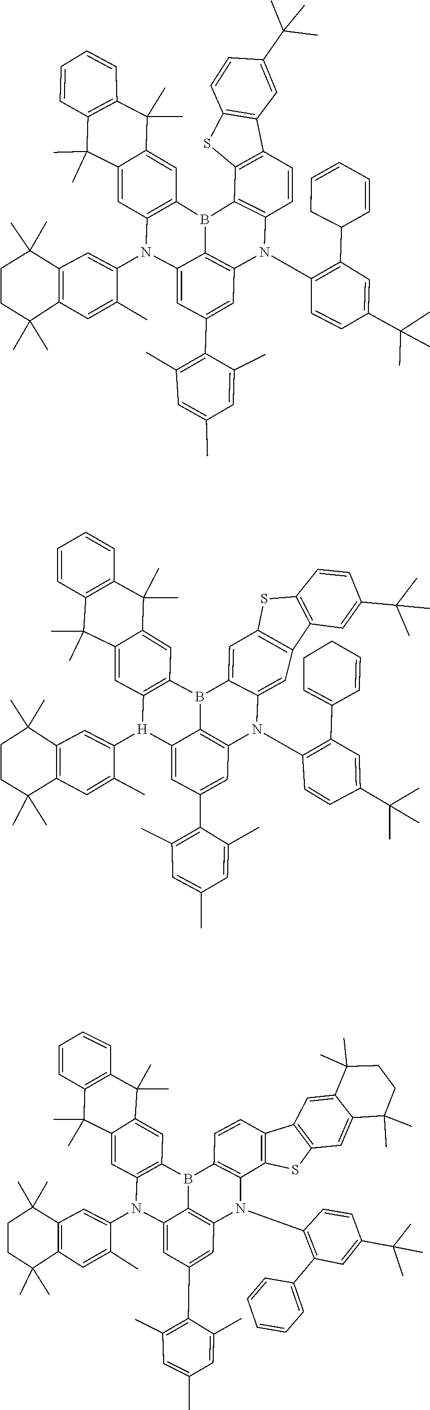

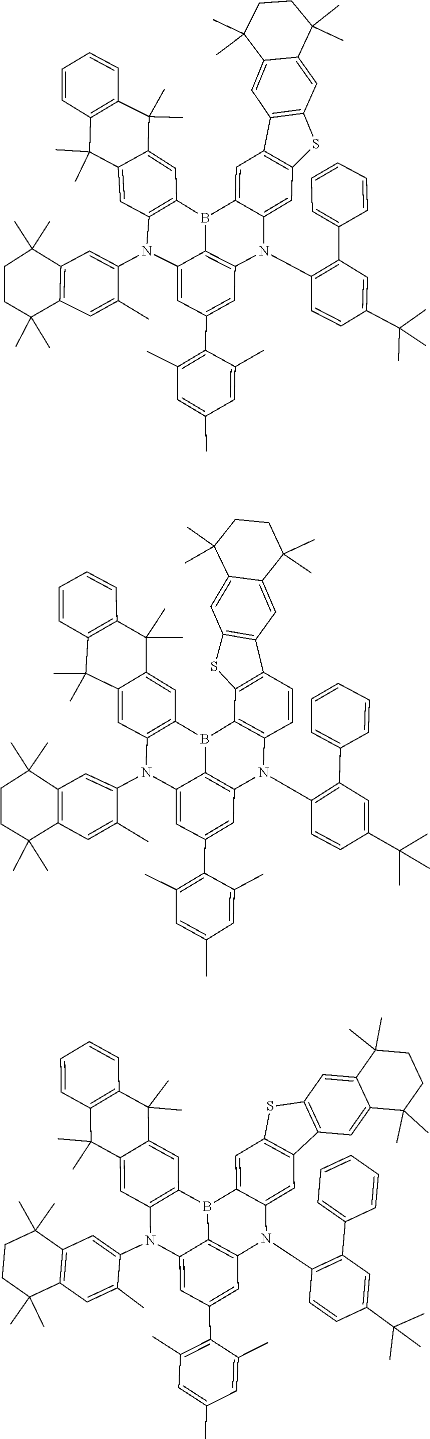 [SMILES: Cc1cc(C)c(-c2cc3c4c(c2)N(c2ccc(C(C)(C)C)cc2-c2ccccc2)c2cc5sc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1 ; Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)sc2cc3c(cc25)C(C)(C)CCC3(C)C)c(C)c1]

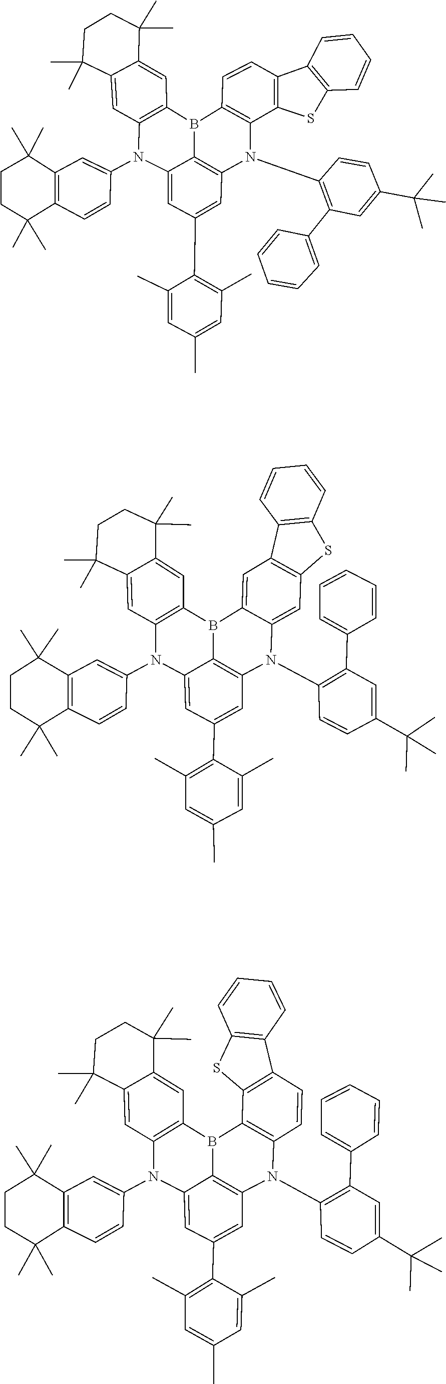 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2ccc3c(c2)C(C)(C)CCC3(C)C)C(C)(C)CCC4(C)C)c(C)c1]

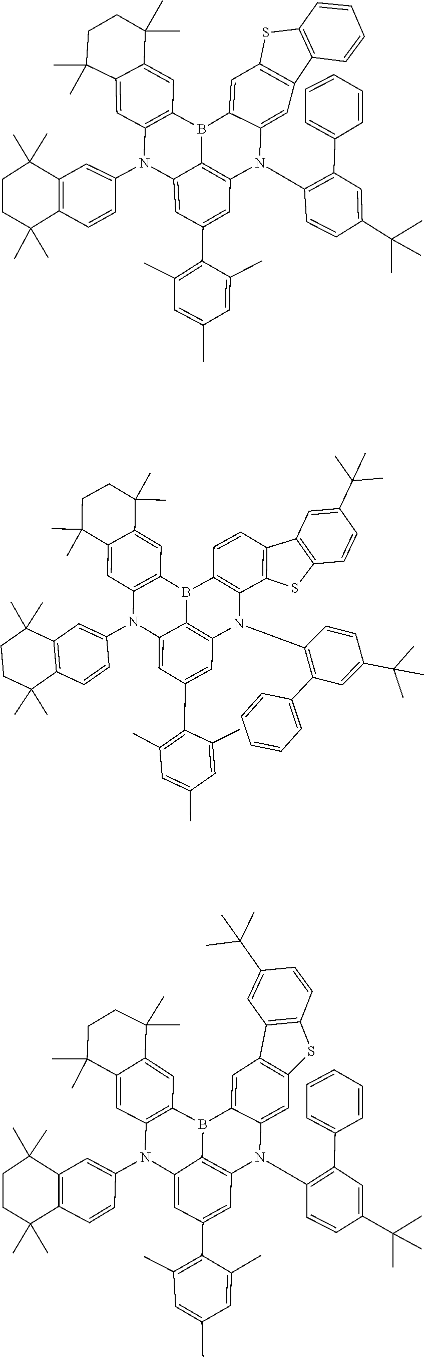 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1]

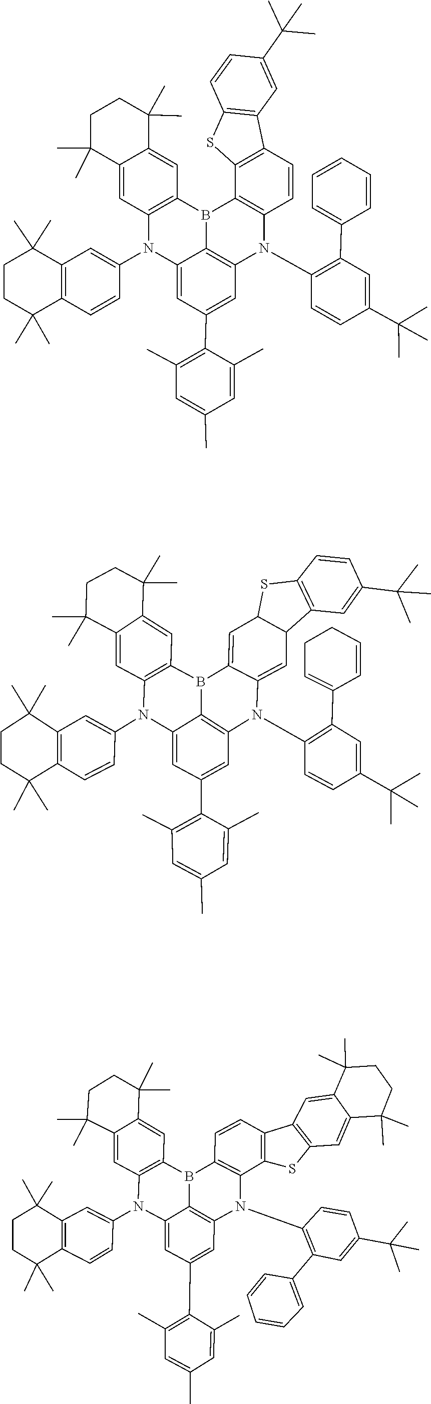 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc5c(c2)C(C)(C)CCC5(C)C)c2cc5c(cc2B4C2=CC4Sc6ccc(C(C)(C)C)cc6C4C=C2N3c2ccc(C(C)(C)C)cc2C2=CCCC=C2)C(C)(C)CCC5(C)C)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1]

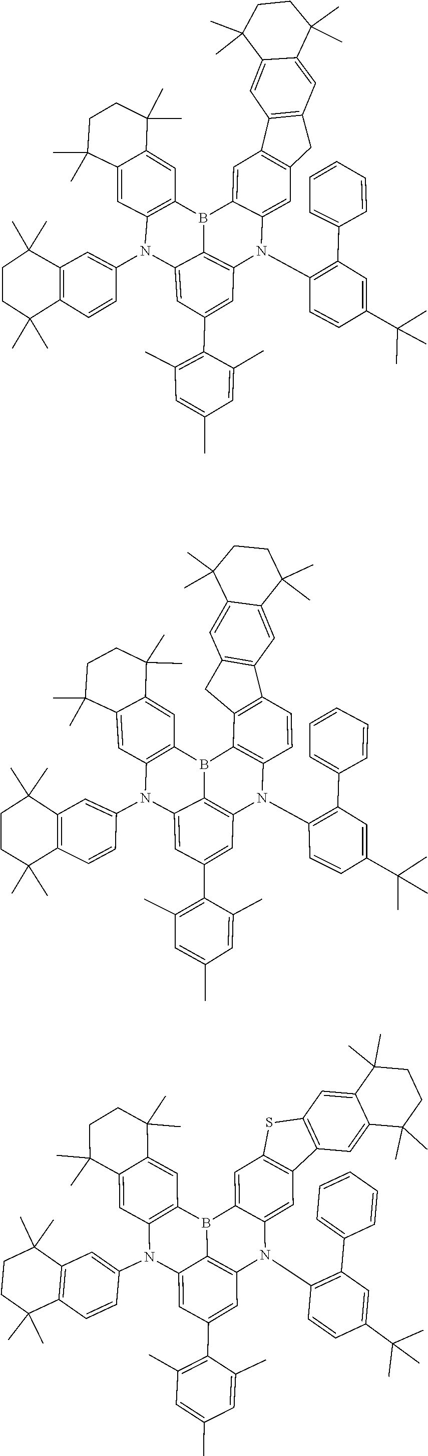 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)-c2cc3c(cc2C5)C(C)(C)CCC3(C)C)c(C)c1 ; Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)CCC3(C)C)C(C)(C)CCC4(C)C)Cc2cc3c(cc2-5)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1]

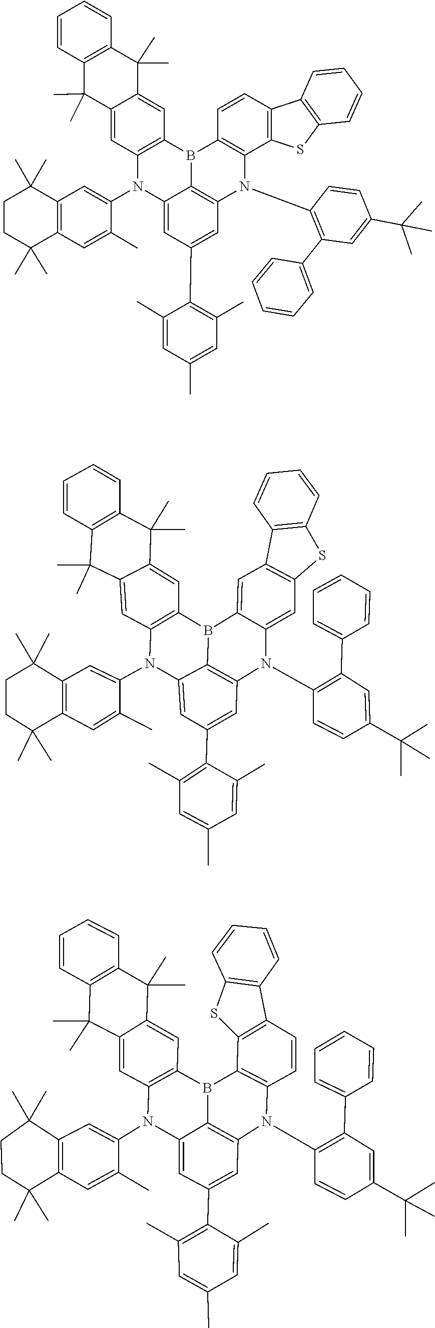 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(sc6ccccc65)c2B4c2cc4c(cc2N3c2cc3c(cc2C)C(C)(C)CCC3(C)C)C(C)(C)c2ccccc2C4(C)C)c(C)c1]

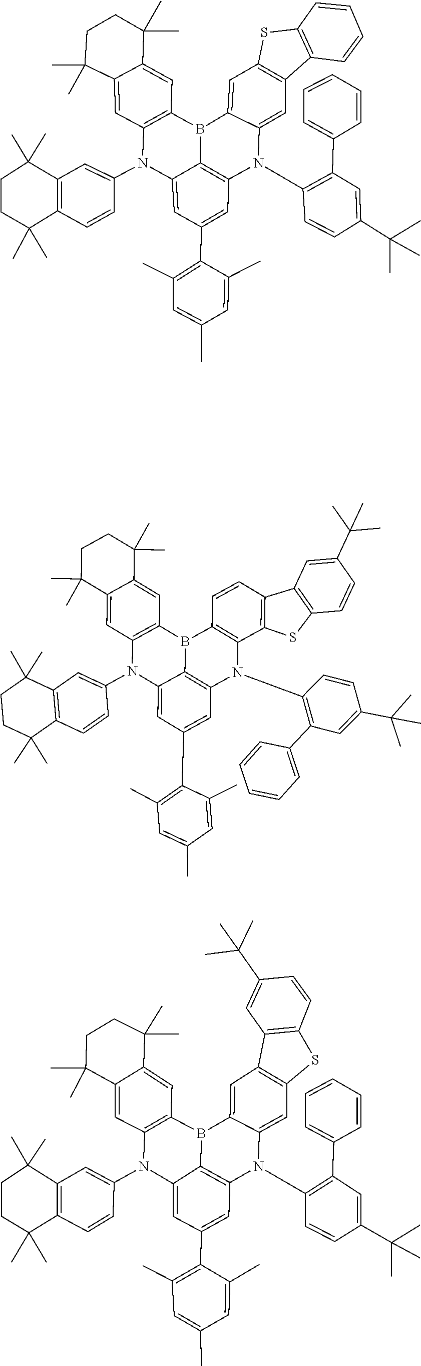 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1]

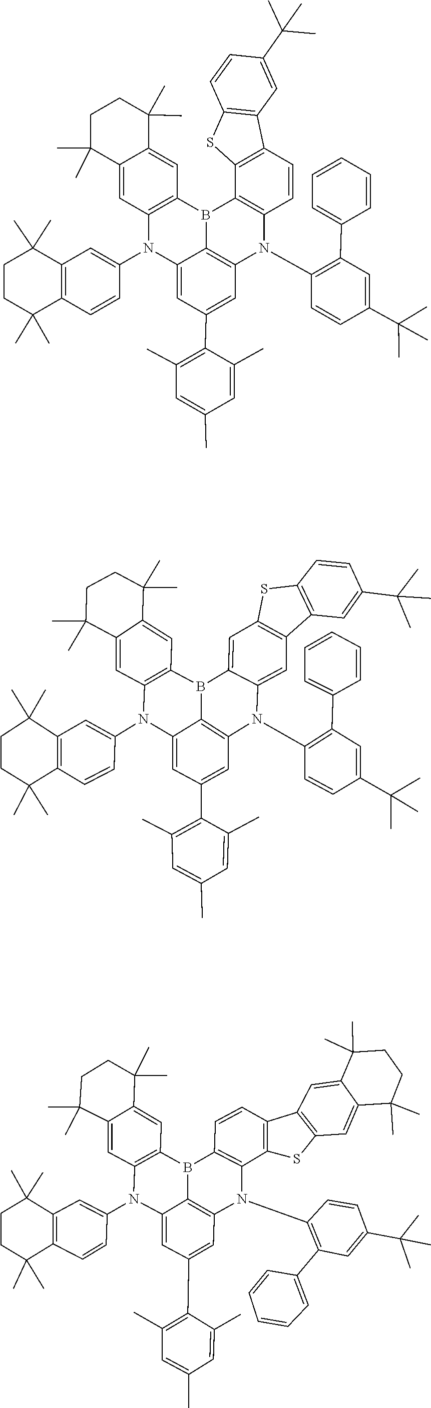 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1]

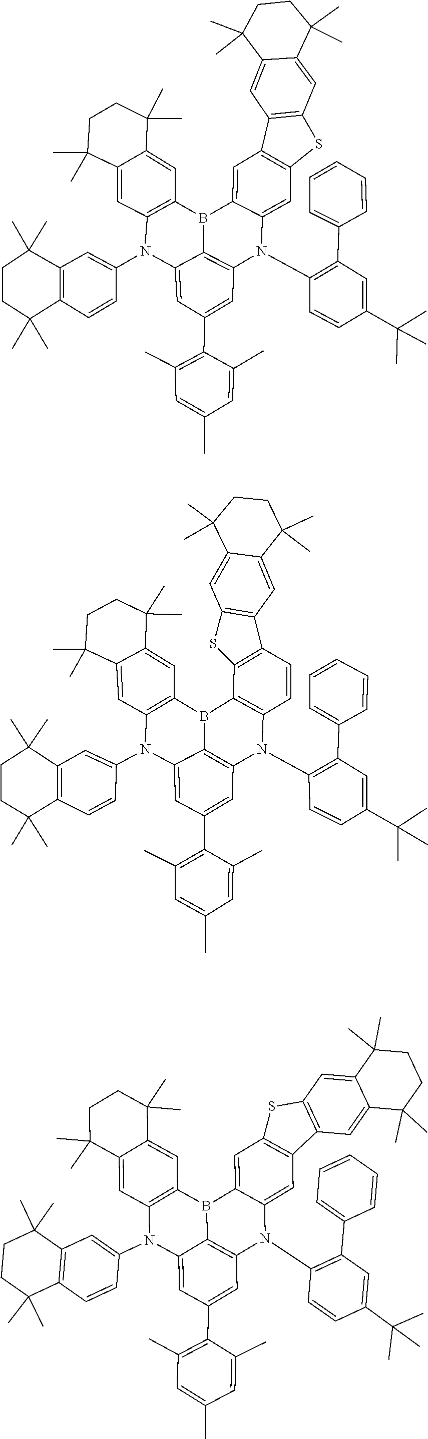 [SMILES: Cc1cc(C)c(-c2cc3c4c(c2)N(c2ccc(C(C)(C)C)cc2-c2ccccc2)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1 ; Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1]

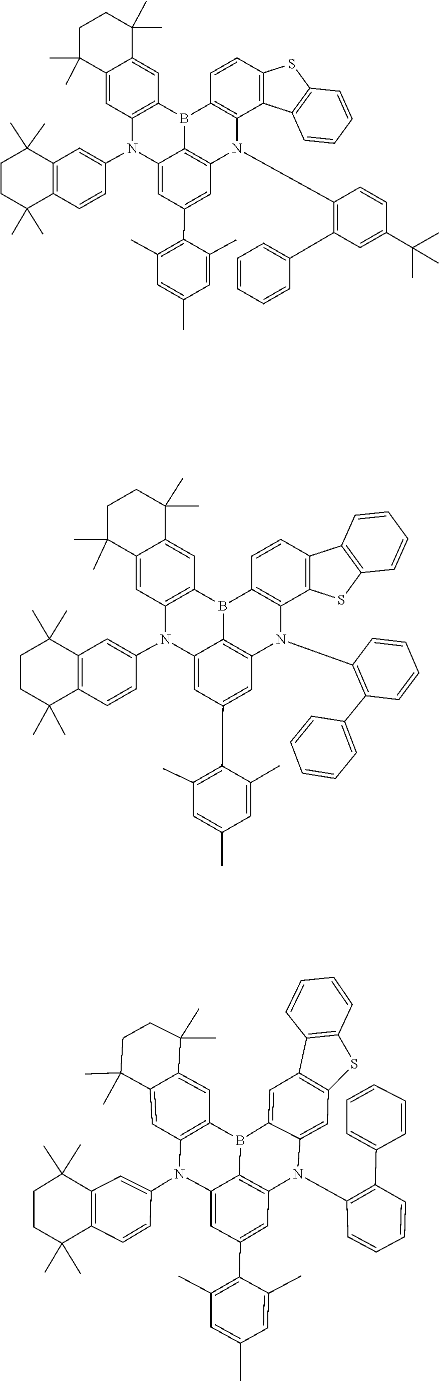 [SMILES: Cc1cc(C)c(-c2cc3c4c(c2)N(c2ccc(C(C)(C)C)cc2-c2ccccc2)c2c(ccc5sc6ccccc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2sc2ccccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5sc6ccccc6c5cc2B4c2cc4c(cc2N3c2ccc3c(c2)C(C)(C)CCC3(C)C)C(C)(C)CCC4(C)C)c(C)c1]

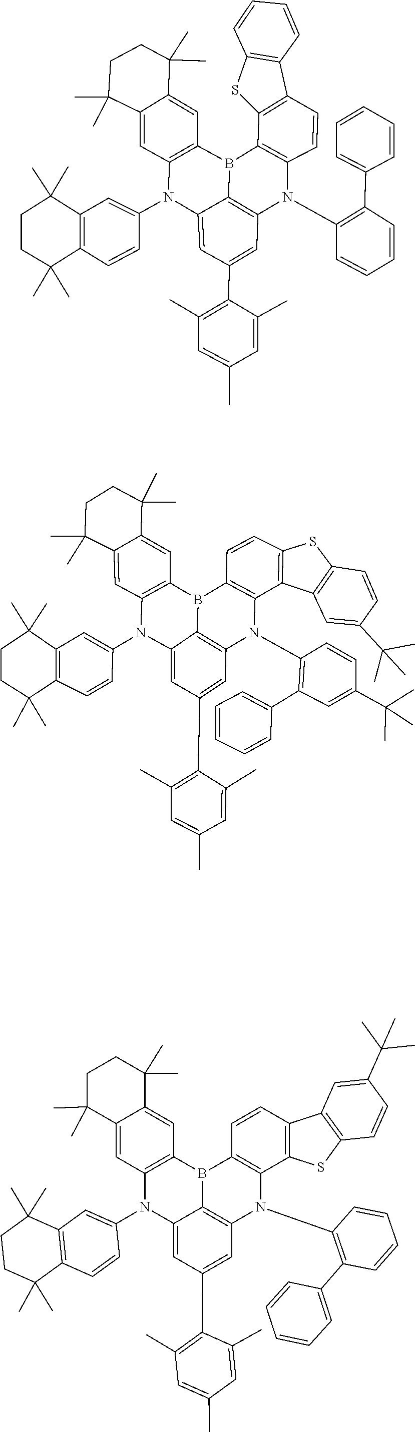 [SMILES: Cc1cc(C)c(-c2cc3c4c(c2)N(c2ccccc2-c2ccccc2)c2ccc5c(sc6ccccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1]

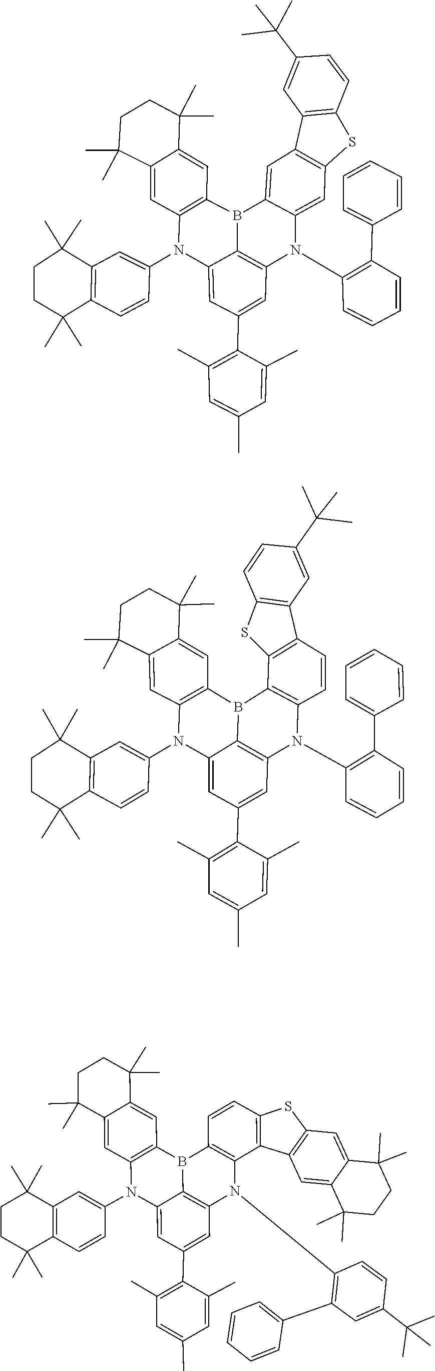 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

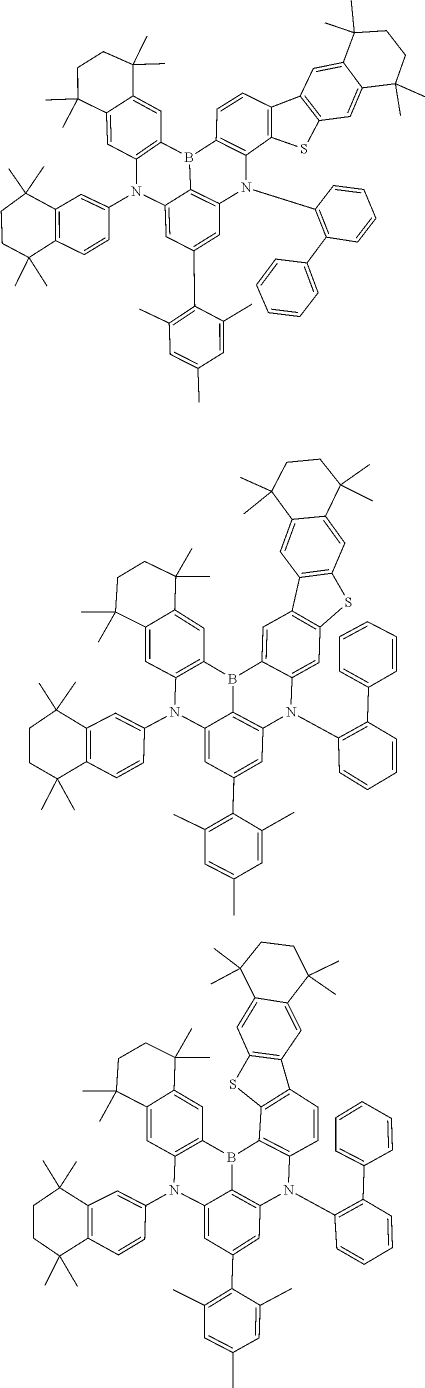

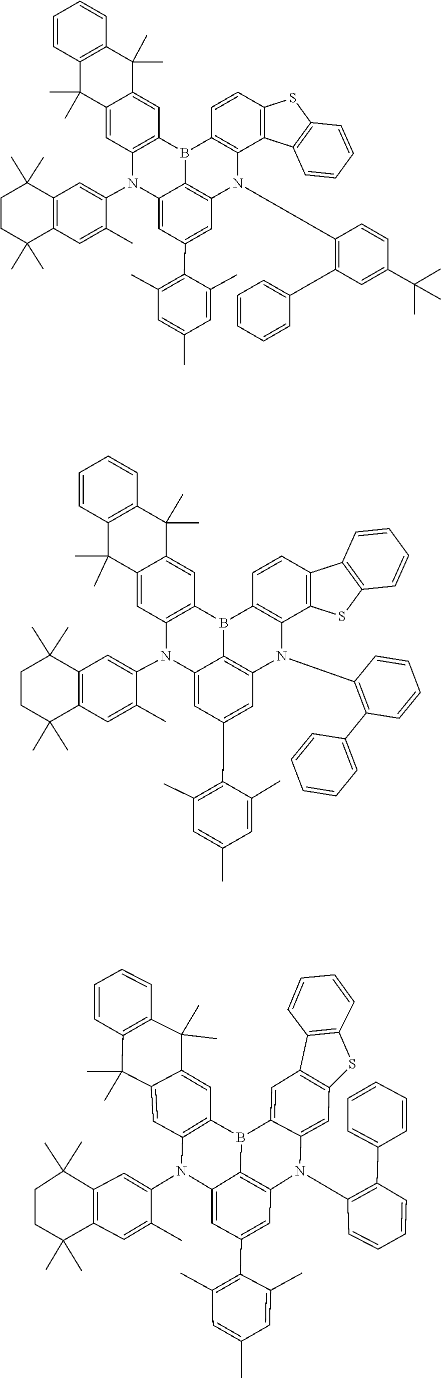 [SMILES: Cc1cc(C)c(-c2cc3c4c(c2)N(c2ccc(C(C)(C)C)cc2-c2ccccc2)c2c(ccc5sc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5sc6ccccc6c5cc2B4c2cc4c(cc2N3c2cc3c(cc2C)C(C)(C)CCC3(C)C)C(C)(C)c2ccccc2C4(C)C)c(C)c1]

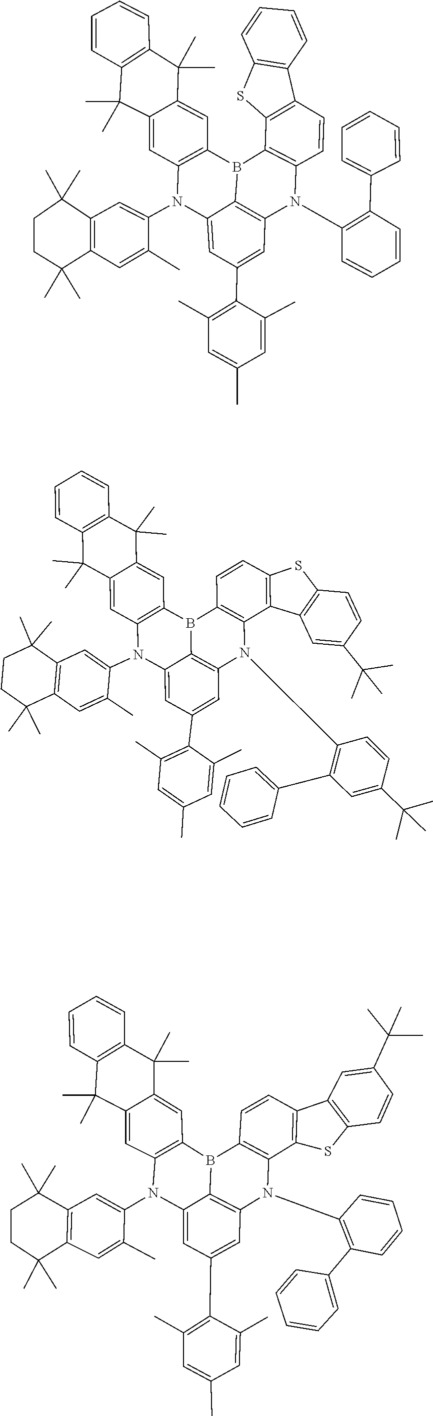 [SMILES: Cc1cc(C)c(-c2cc3c4c(c2)N(c2ccccc2-c2ccccc2)c2ccc5c(sc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1]

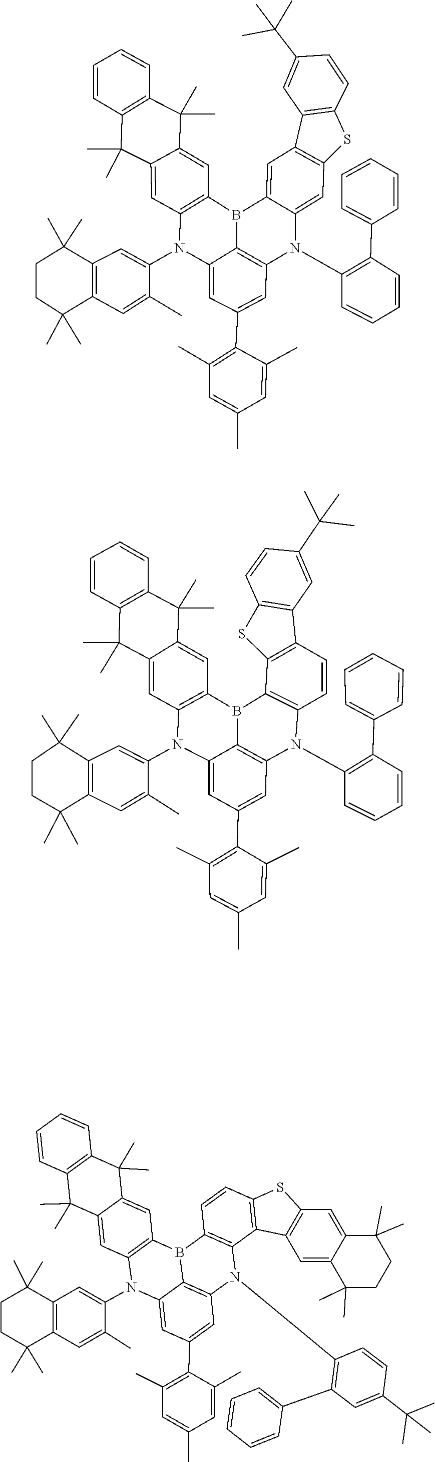 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1]

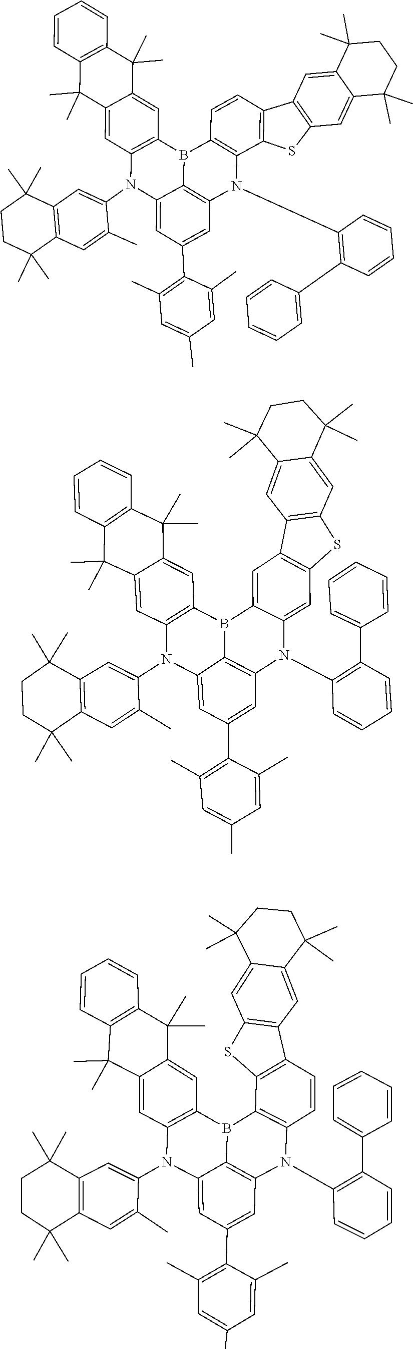 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1]

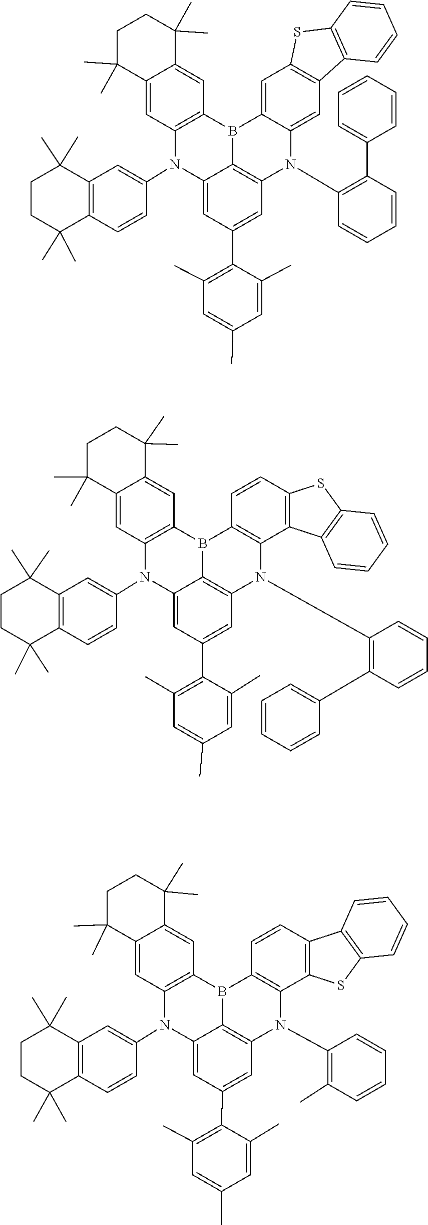 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2sc2ccccc25)B4c2cc4c(cc2N3c2ccc3c(c2)C(C)(C)CCC3(C)C)C(C)(C)CCC4(C)C)c(C)c1]

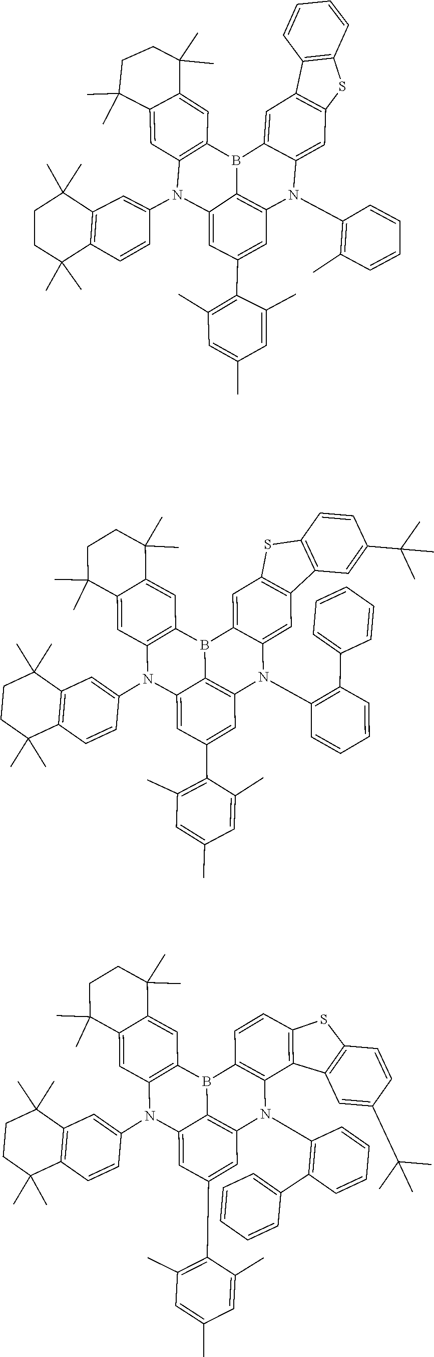 [SMILES: Cc1cc(C)c(-c2cc3c4c(c2)N(c2ccccc2C)c2cc5sc6ccccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1 ; Cc1cc(C)c(-c2cc3c4c(c2)N(c2ccccc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1]

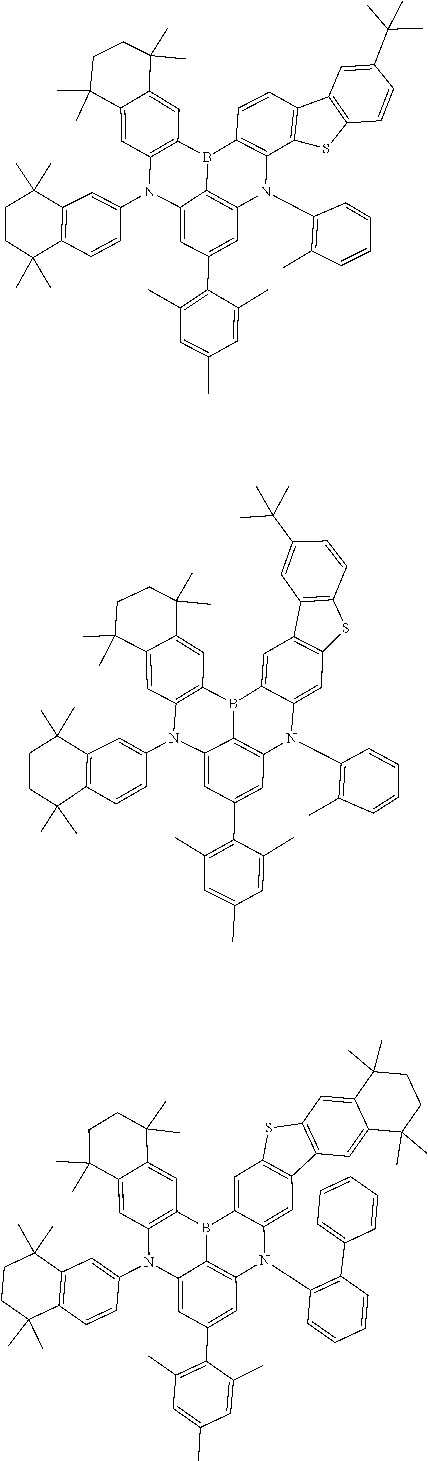 [SMILES: Cc1cc(C)c(-c2cc3c4c(c2)N(c2ccccc2C)c2c(ccc5c2sc2ccc(C(C)(C)C)cc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1]

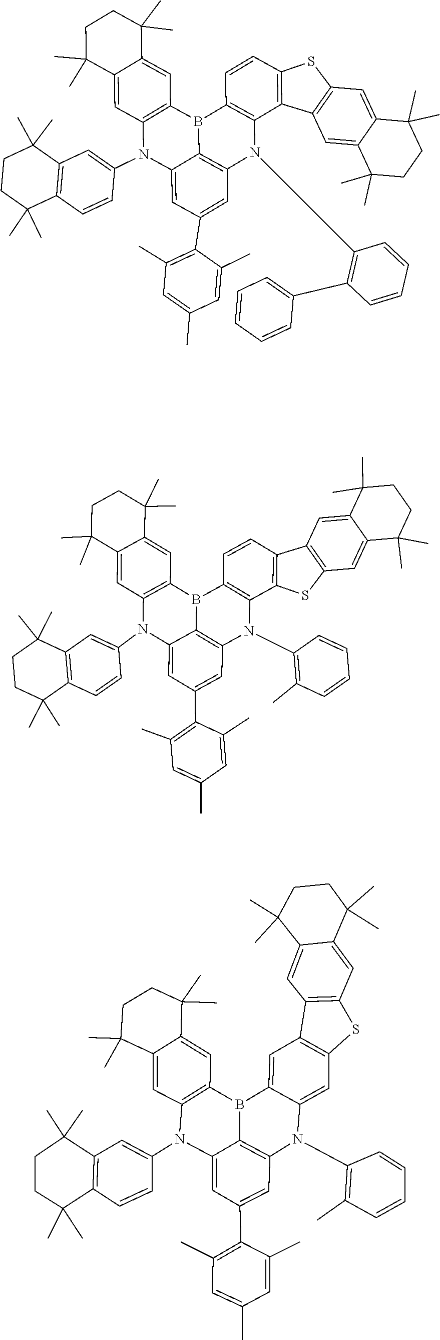 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

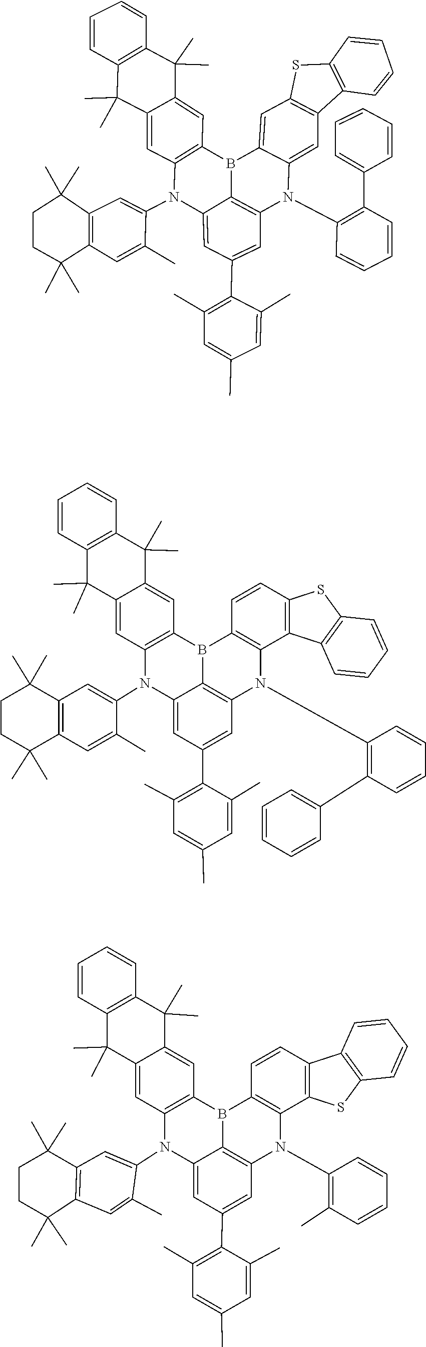 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2sc2ccccc25)B4c2cc4c(cc2N3c2cc3c(cc2C)C(C)(C)CCC3(C)C)C(C)(C)c2ccccc2C4(C)C)c(C)c1]

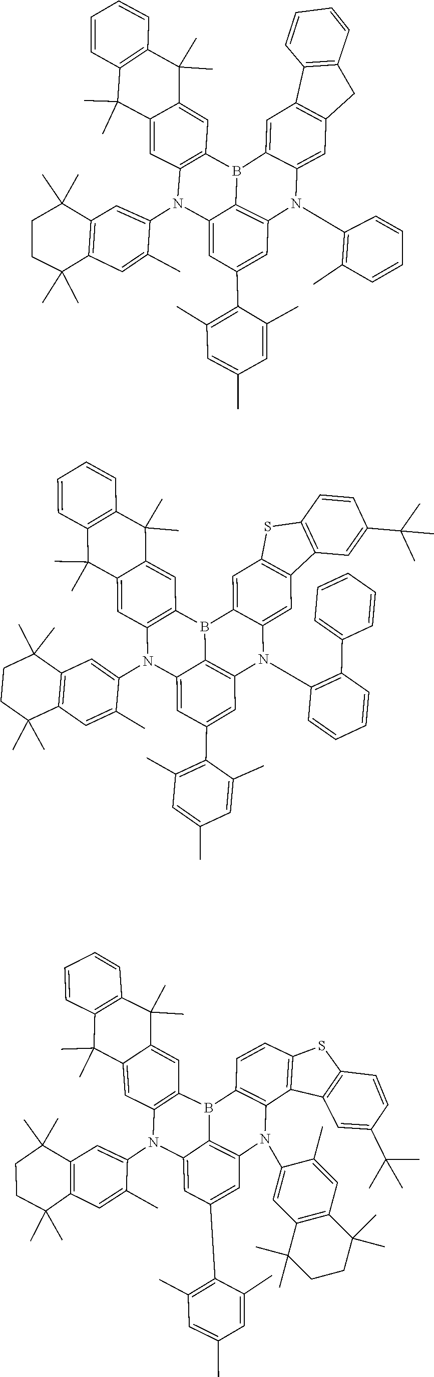 [SMILES: Cc1cc(C)c(-c2cc3c4c(c2)N(c2cc5c(cc2C)C(C)(C)CCC5(C)C)c2cc5c(cc2B4c2cc4c(cc2N3c2ccccc2C)Cc2ccccc2-4)C(C)(C)c2ccccc2C5(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1]

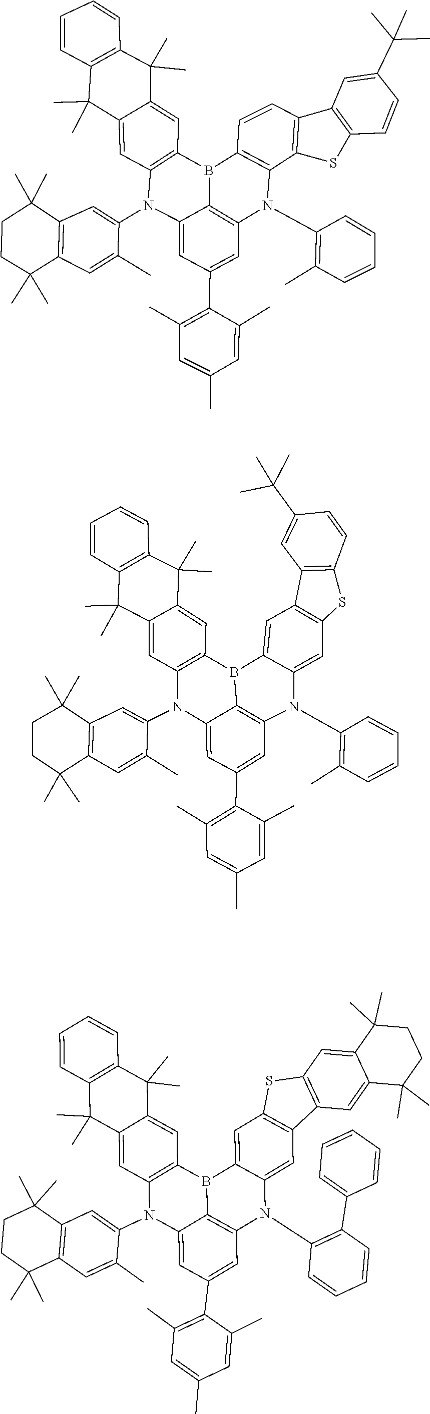 [SMILES: Cc1cc(C)c(-c2cc3c4c(c2)N(c2ccccc2C)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)sc2cc3c(cc25)C(C)(C)CCC3(C)C)c(C)c1]

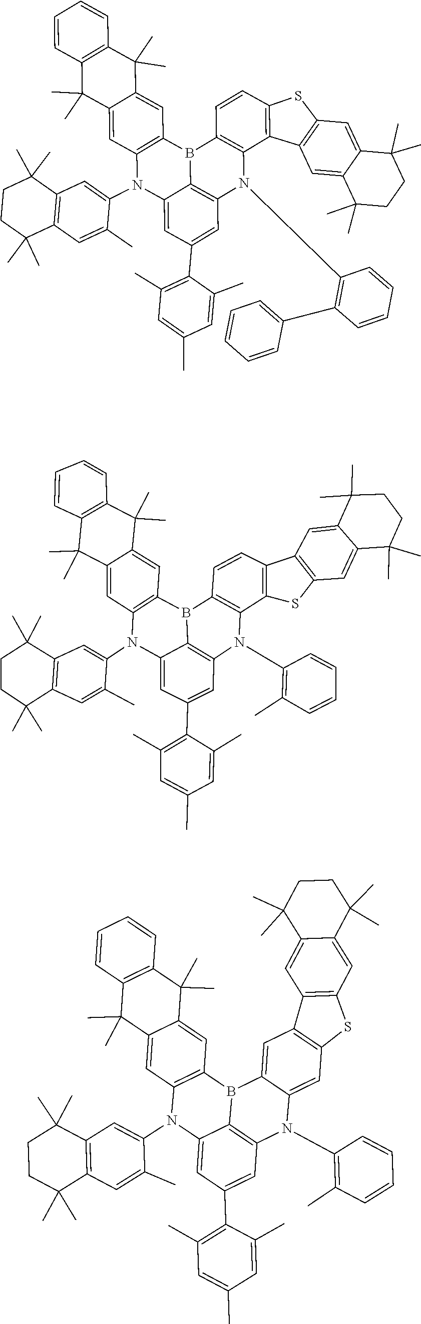 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5sc6cc7c(cc6c5cc2B4c2cc4c(cc2N3c2cc3c(cc2C)C(C)(C)CCC3(C)C)C(C)(C)c2ccccc2C4(C)C)C(C)(C)CCC7(C)C)c(C)c1]

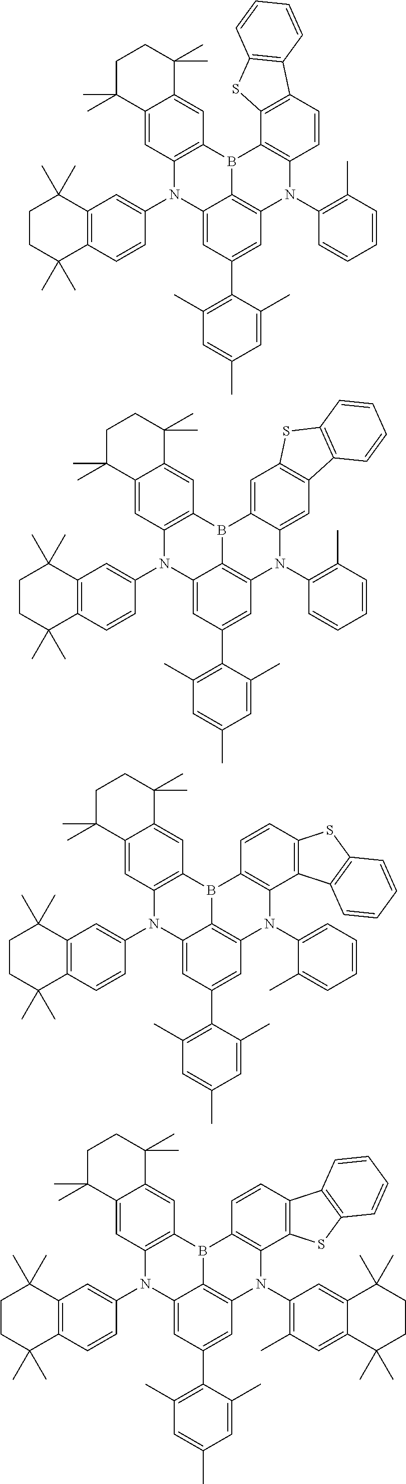

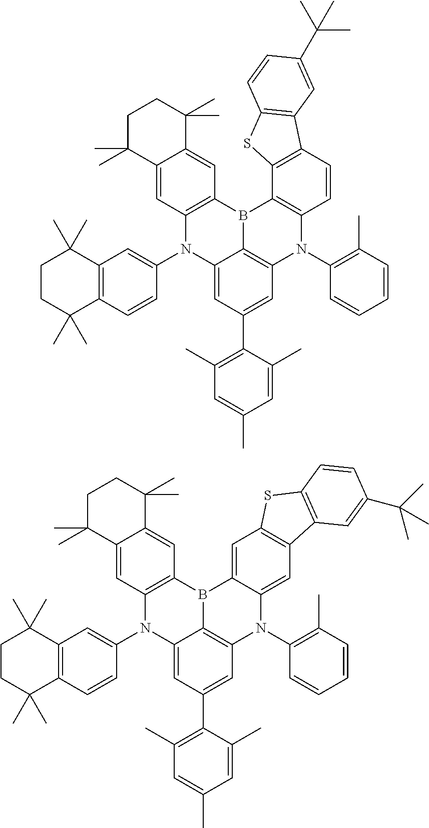 [SMILES: Cc1cc(C)c(-c2cc3c4c(c2)N(c2ccccc2C)c2ccc5c(sc6ccc(C(C)(C)C)cc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1]

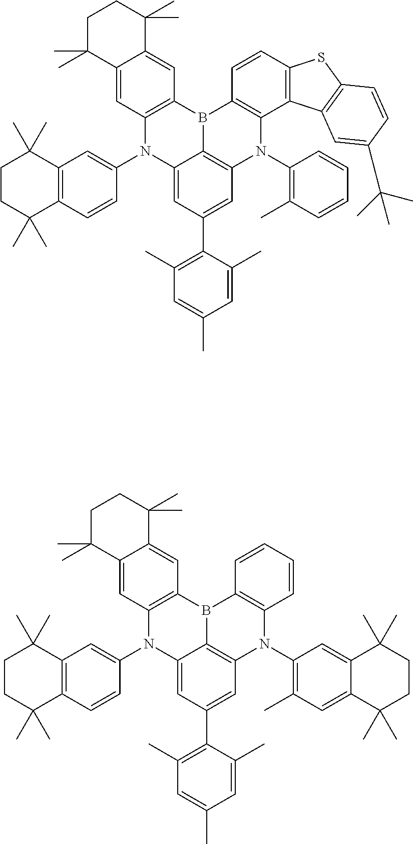 [SMILES: Cc1cc(C)c(-c2cc3c4c(c2)N(c2ccccc2C)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2ccccc2B4c2cc4c(cc2N3c2ccc3c(c2)C(C)(C)CCC3(C)C)C(C)(C)CCC4(C)C)c(C)c1]

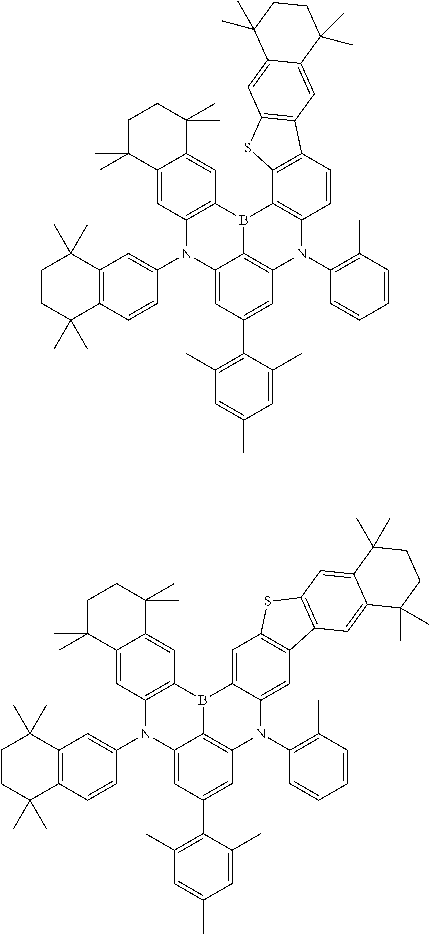 [SMILES: Cc1cc(C)c(-c2cc3c4c(c2)N(c2ccccc2C)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1]

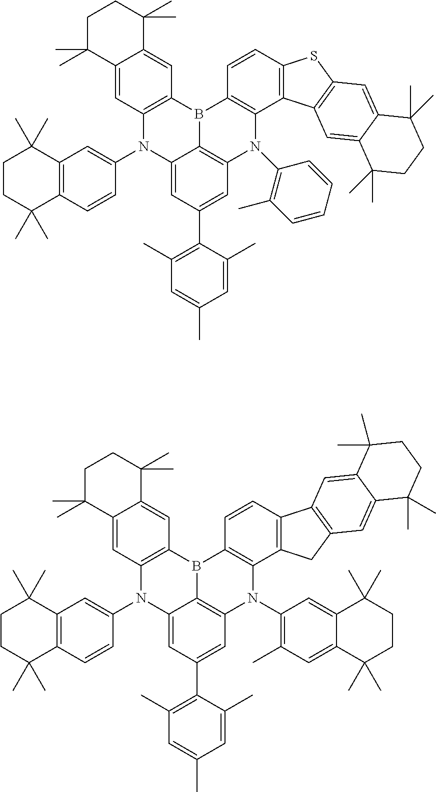 [SMILES: Cc1cc(C)c(-c2cc3c4c(c2)N(c2ccccc2C)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5c2Cc2cc6c(cc2-5)C(C)(C)CCC6(C)C)B4c2cc4c(cc2N3c2ccc3c(c2)C(C)(C)CCC3(C)C)C(C)(C)CCC4(C)C)c(C)c1]

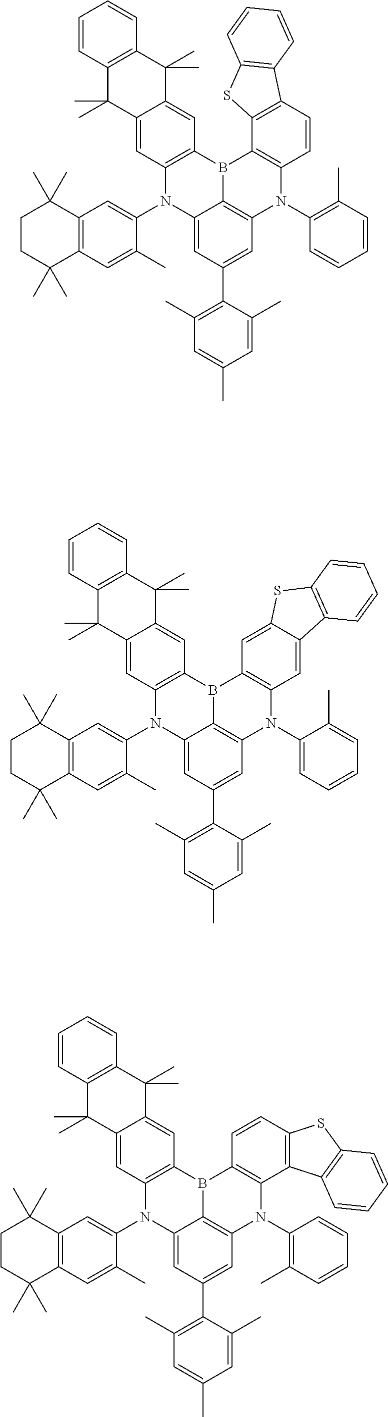 [SMILES: Cc1cc(C)c(-c2cc3c4c(c2)N(c2ccccc2C)c2ccc5c(sc6ccccc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2cc3c(cc2C)C(C)(C)CCC3(C)C)C(C)(C)c2ccccc2C4(C)C)c(C)c1]

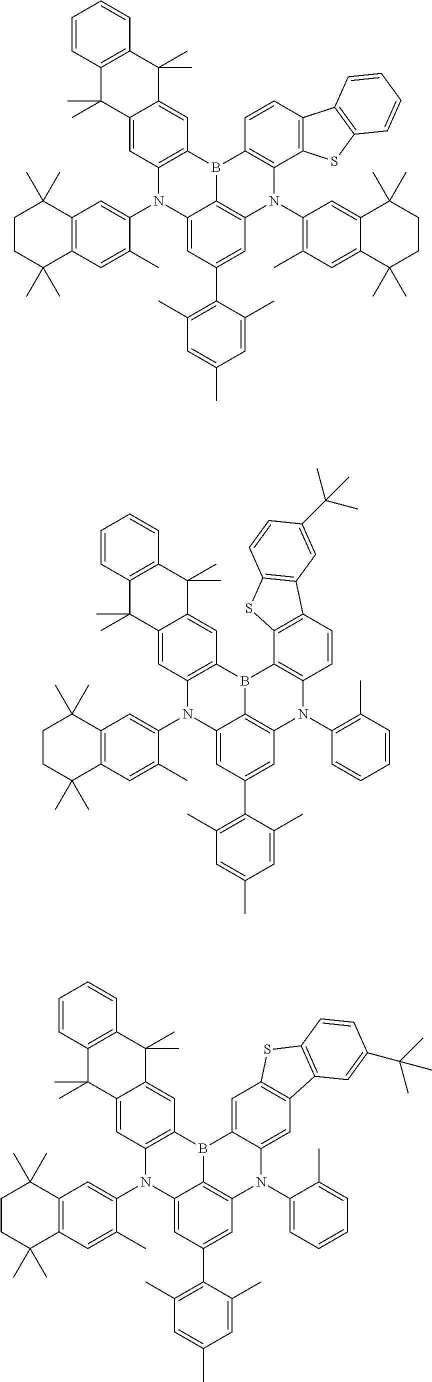 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)c2ccccc2C4(C)C)sc2ccc(C(C)(C)C)cc25)c(C)c1]

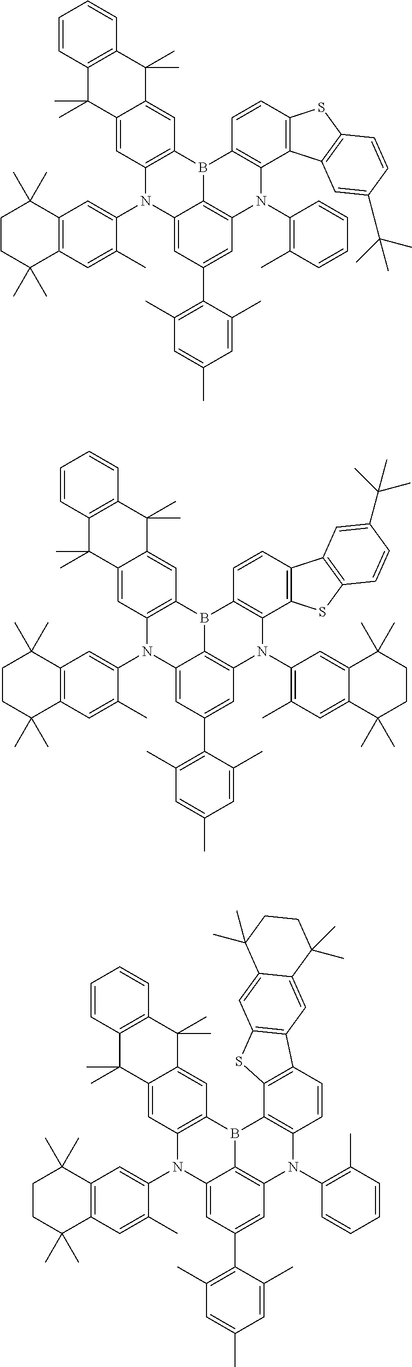 [SMILES: Cc1cc(C)c(-c2cc3c4c(c2)N(c2ccccc2C)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(sc6cc7c(cc65)C(C)(C)CCC7(C)C)c2B4c2cc4c(cc2N3c2cc3c(cc2C)C(C)(C)CCC3(C)C)C(C)(C)c2ccccc2C4(C)C)c(C)c1]

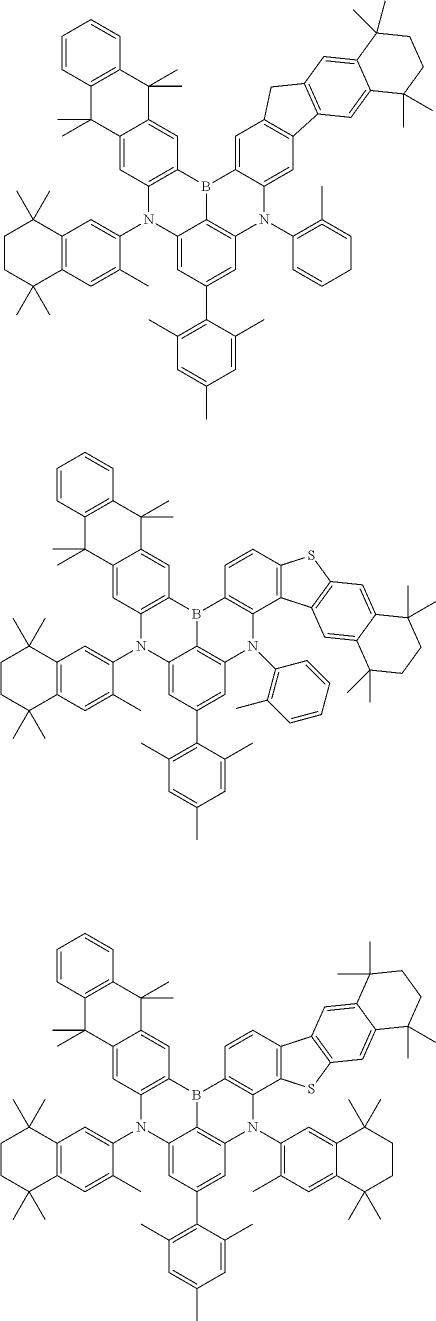

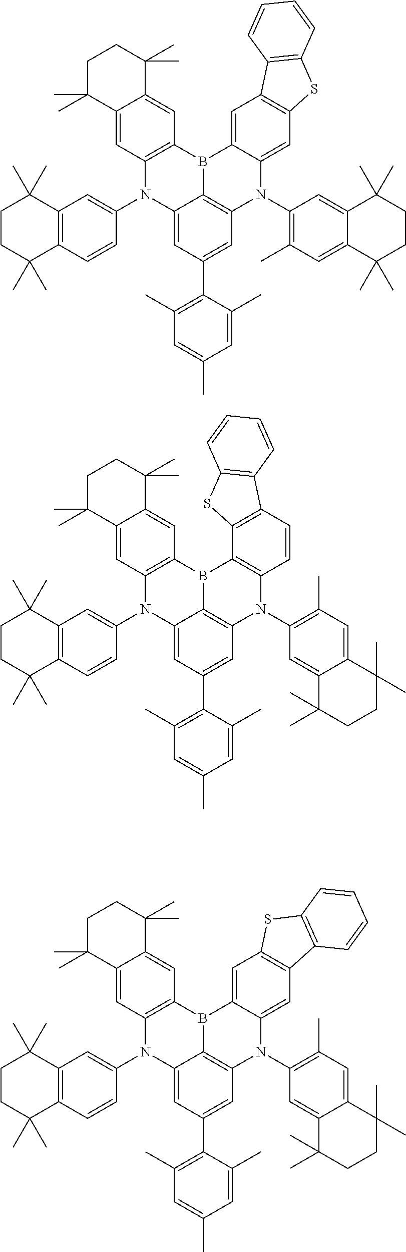

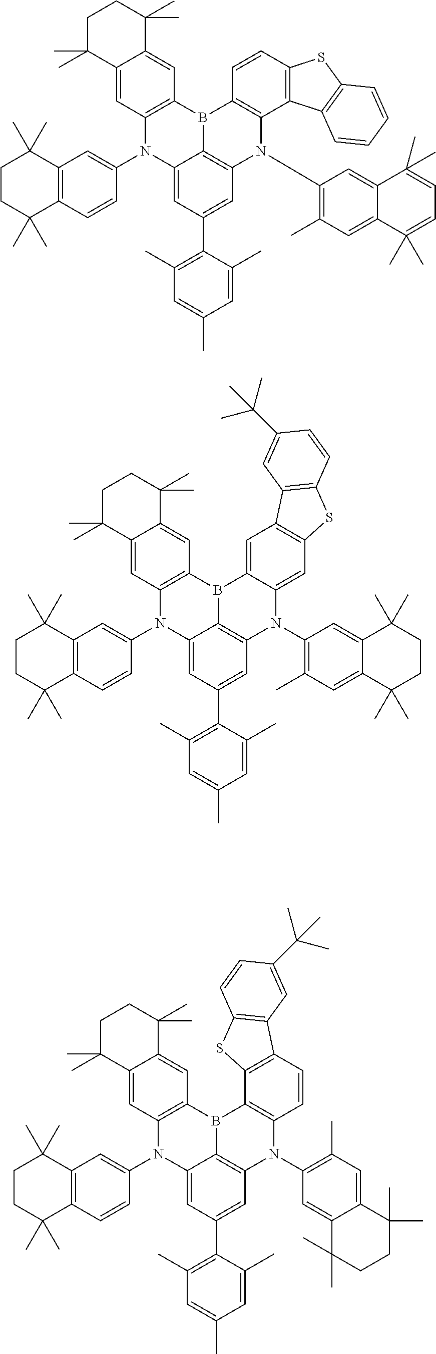

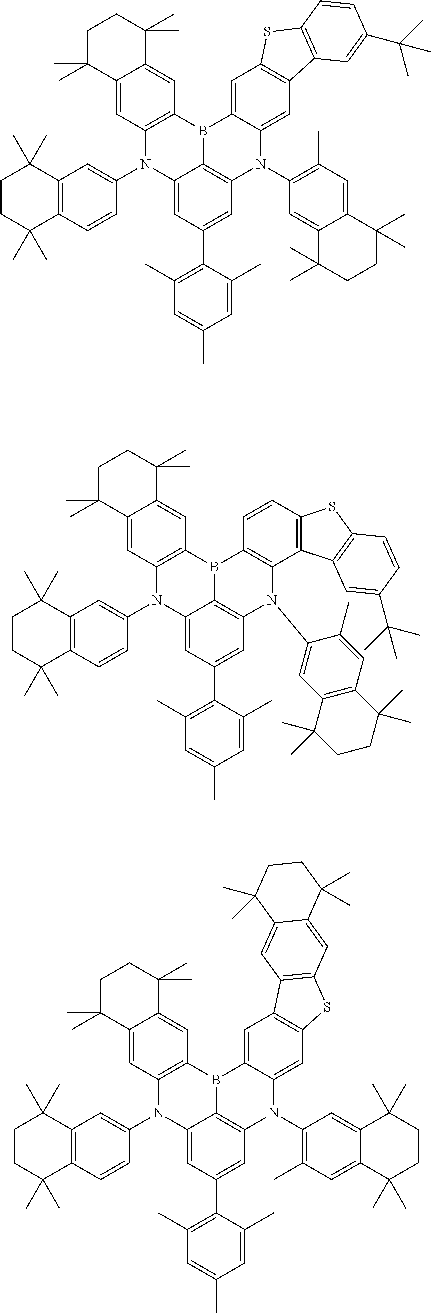 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)c(C)c1]

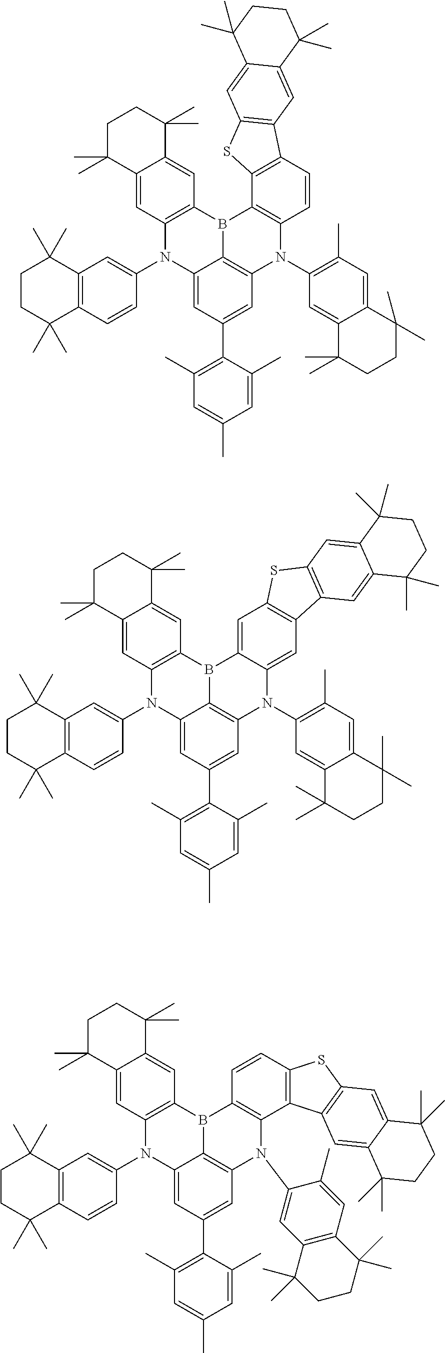 [SMILES: Cc1cc(C)c(-c2cc3c4c(c2)N(c2cc5c(cc2C)C(C)(C)CCC5(C)C)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5sc6cc7c(cc6c25)C(C)(C)CCC7(C)C)B4c2cc4c(cc2N3c2ccc3c(c2)C(C)(C)CCC3(C)C)C(C)(C)CCC4(C)C)c(C)c1]

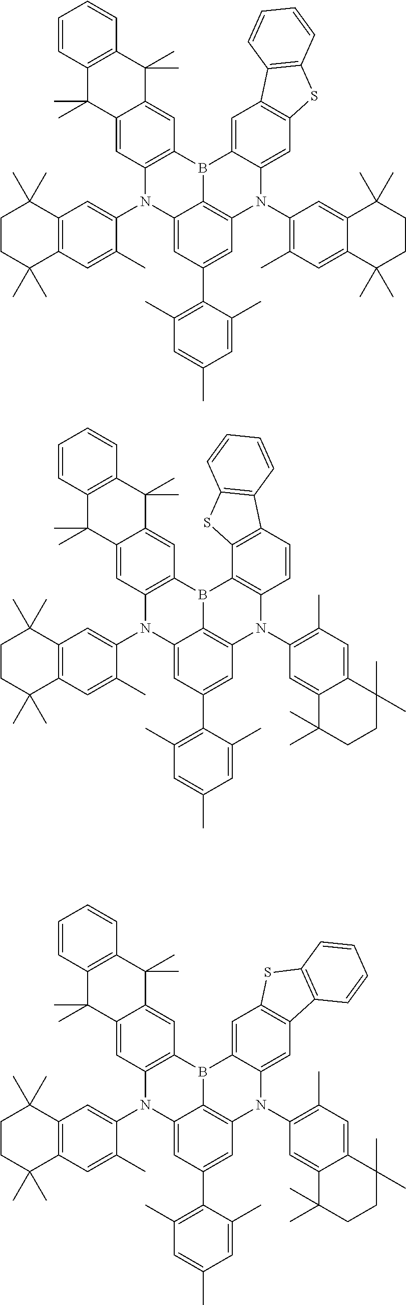

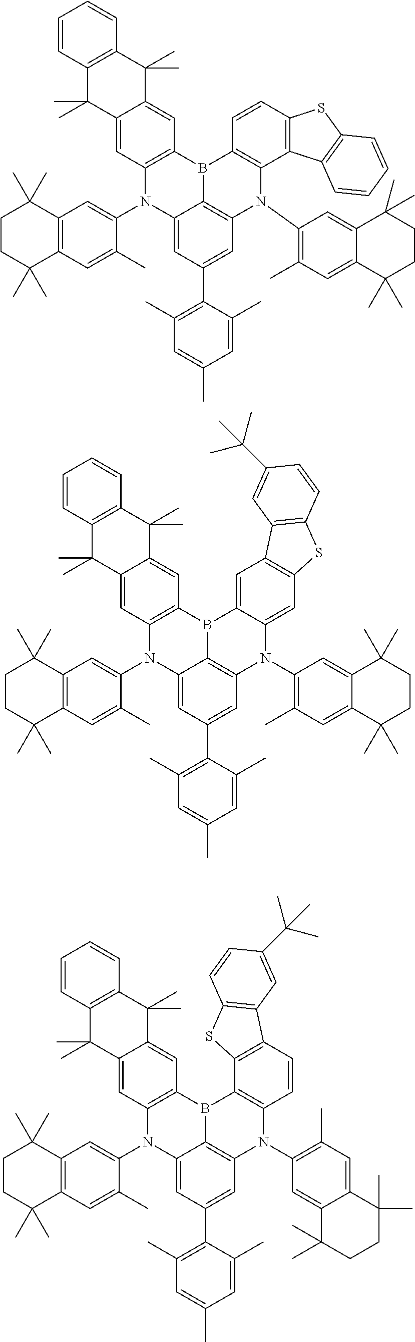

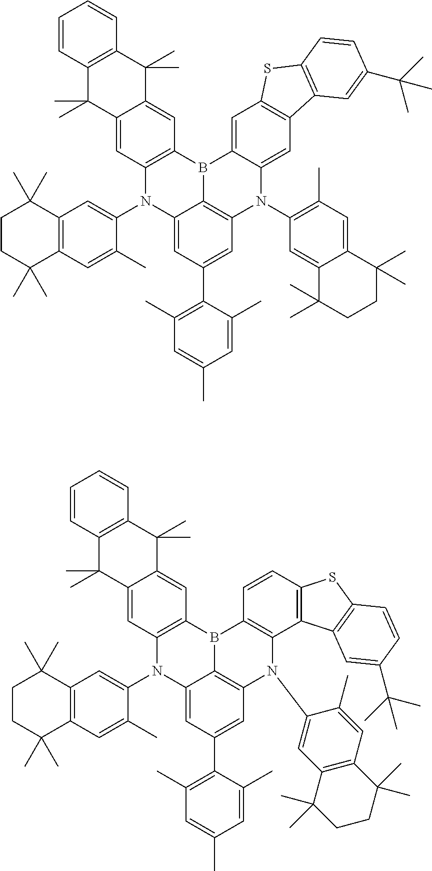 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)sc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5sc6ccc(C(C)(C)C)cc6c25)B4c2cc4c(cc2N3c2cc3c(cc2C)C(C)(C)CCC3(C)C)C(C)(C)c2ccccc2C4(C)C)c(C)c1]

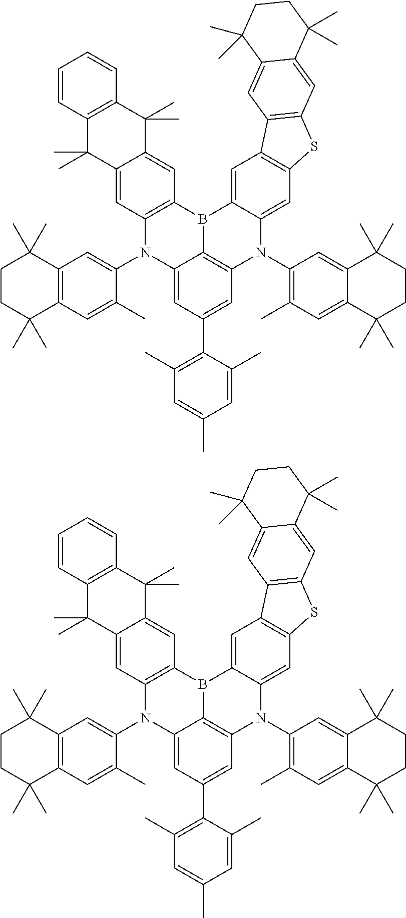

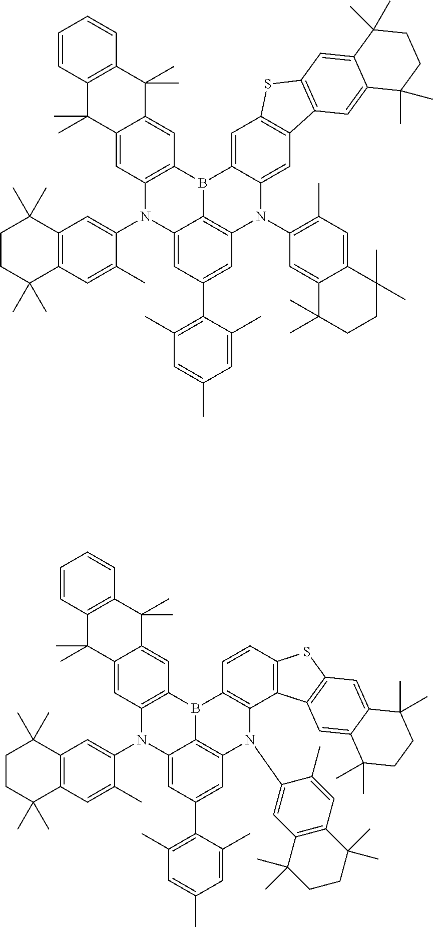 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2ccccc2C4(C)C)sc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5sc6cc7c(cc6c25)C(C)(C)CCC7(C)C)B4c2cc4c(cc2N3c2cc3c(cc2C)C(C)(C)CCC3(C)C)C(C)(C)c2ccccc2C4(C)C)c(C)c1]

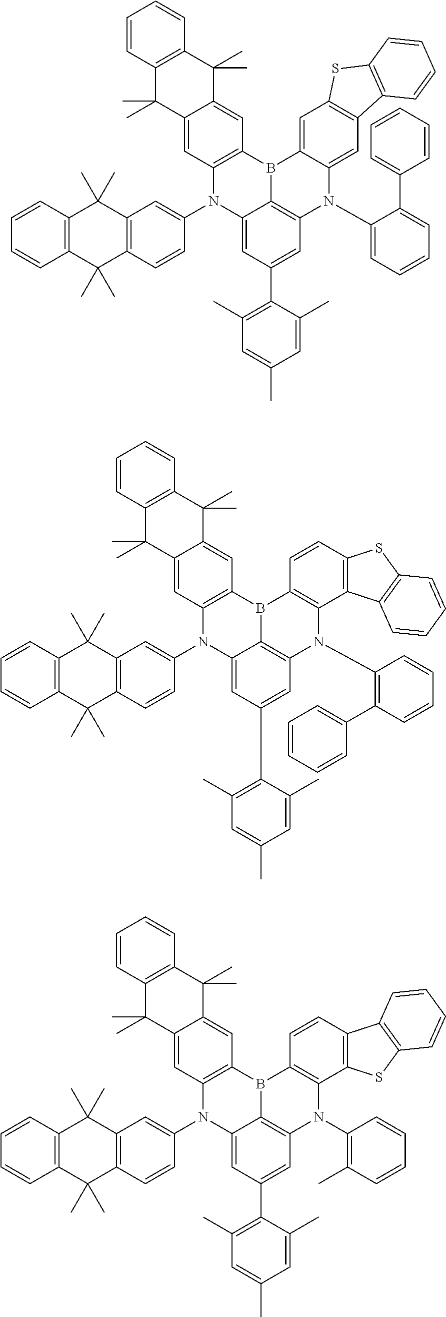 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1]

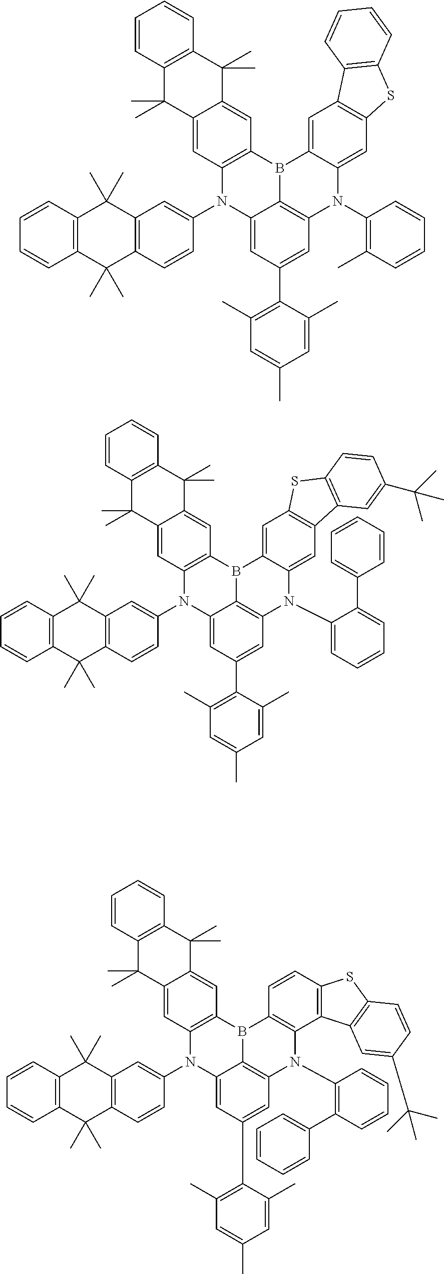 [SMILES: Cc1cc(C)c(-c2cc3c4c(c2)N(c2ccccc2C)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1 ; Cc1cc(C)c(-c2cc3c4c(c2)N(c2ccccc2-c2ccccc2)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1]

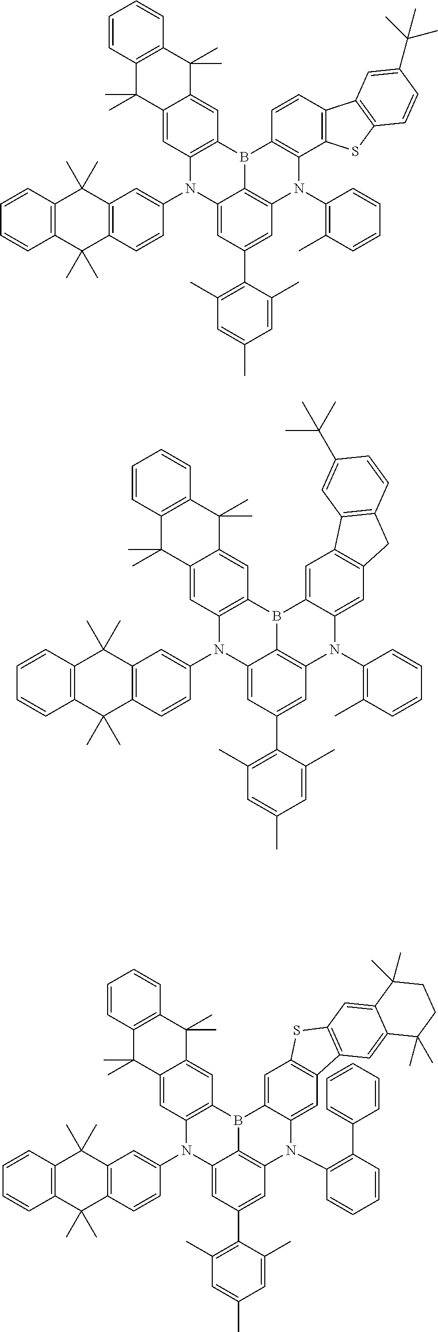 [SMILES: Cc1cc(C)c(-c2cc3c4c(c2)N(c2ccccc2C)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)-c2cc(C(C)(C)C)ccc2C5)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2cc3c(cc25)C(C)(C)CCC3(C)C)c(C)c1]

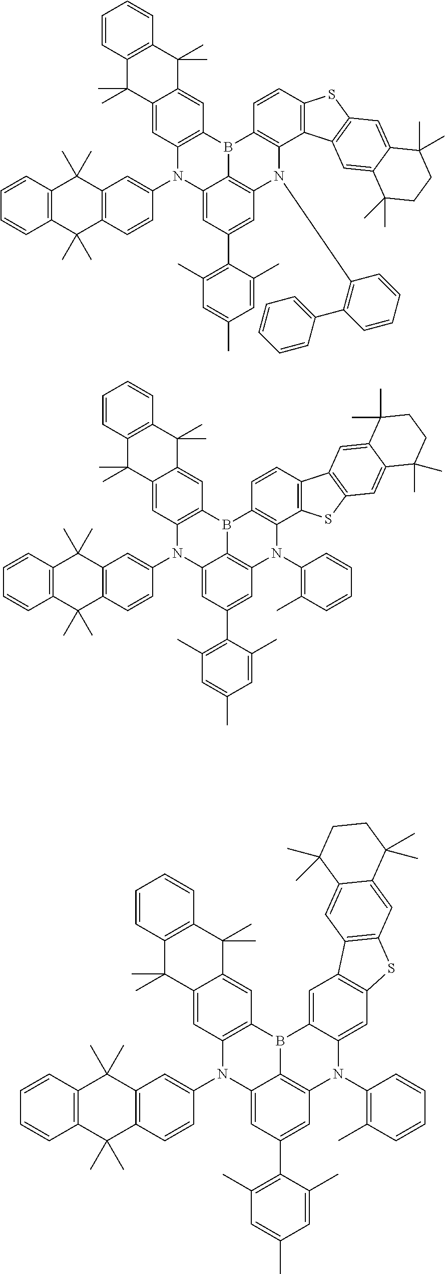 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5sc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1]

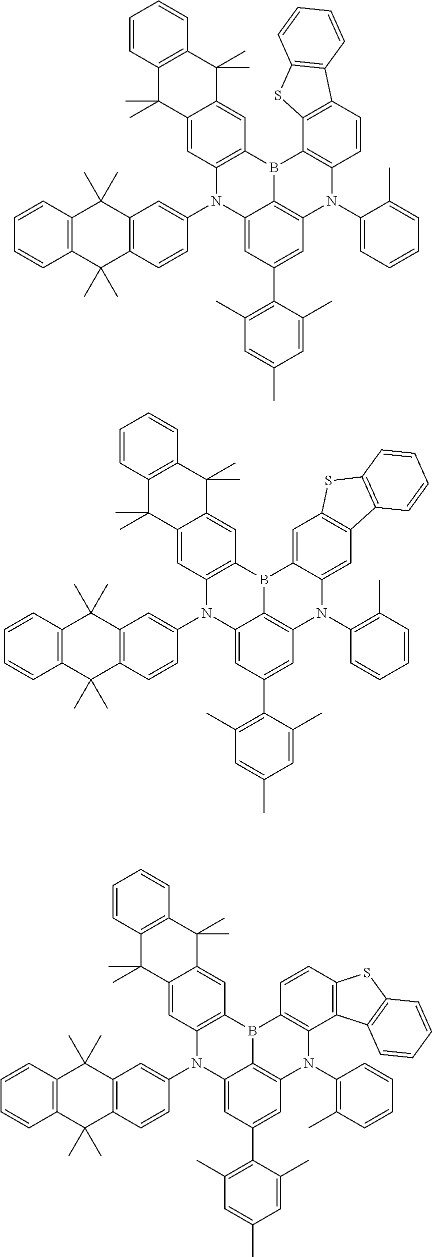 [SMILES: Cc1cc(C)c(-c2cc3c4c(c2)N(c2ccccc2C)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1]

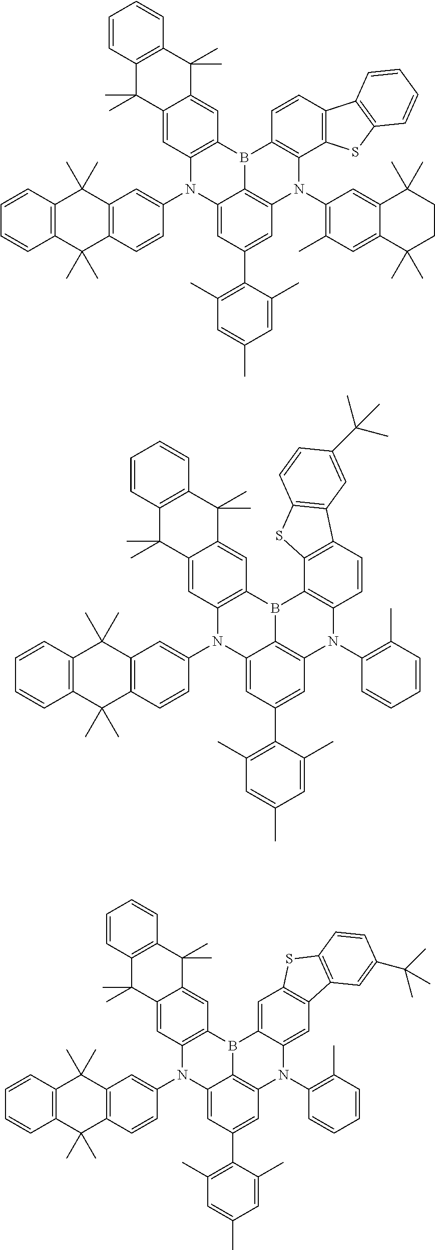 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1]

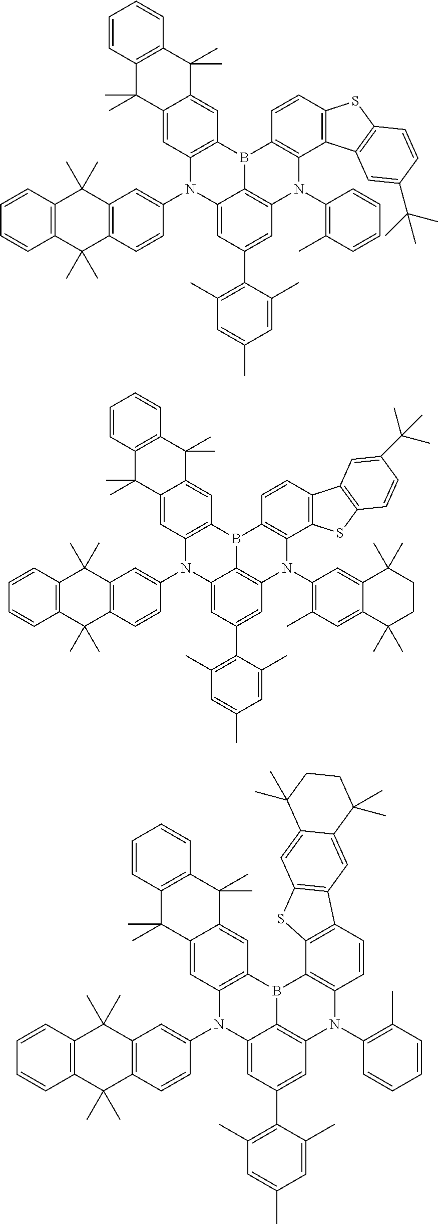 [SMILES: Cc1cc(C)c(-c2cc3c4c(c2)N(c2ccccc2C)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(sc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

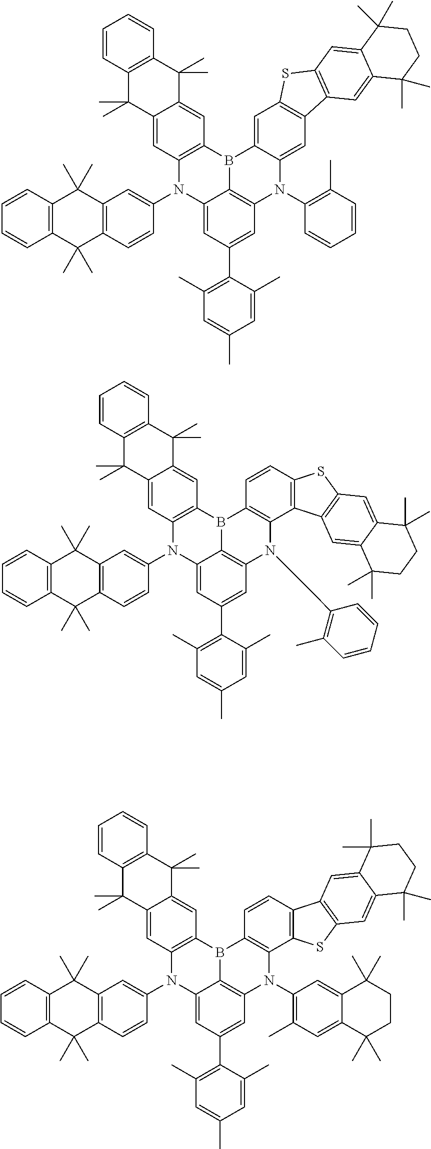 [SMILES: Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)sc2cc3c(cc25)C(C)(C)CCC3(C)C)c(C)c1 ; Cc1cc(C)c(-c2cc3c4c(c2)N(c2ccccc2C)c2c(ccc5sc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

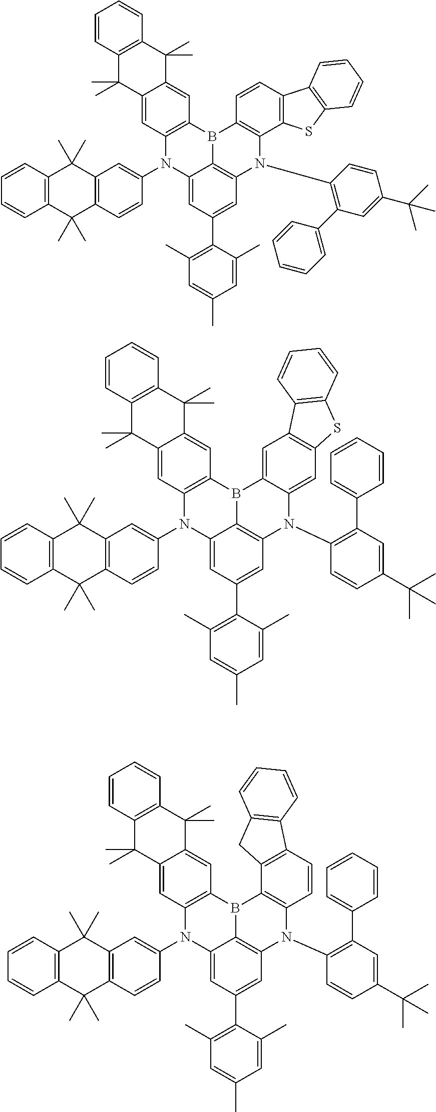 [SMILES: Cc1cc(C)c(-c2cc3c4c(c2)N(c2ccc(C(C)(C)C)cc2-c2ccccc2)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)c2ccccc2C3(C)C)C(C)(C)c2ccccc2C4(C)C)Cc2ccccc2-5)c(C)c1]

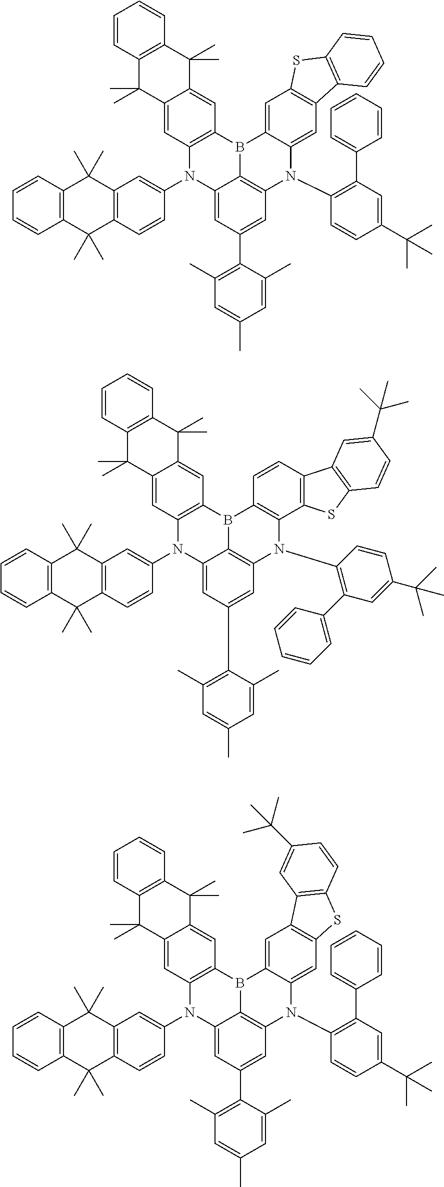 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1]

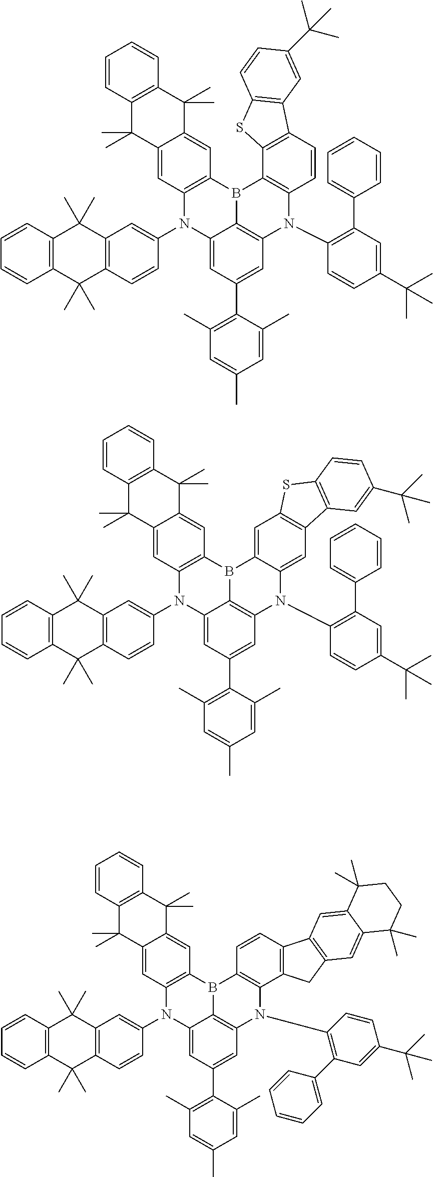 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2Cc2cc6c(cc2-5)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

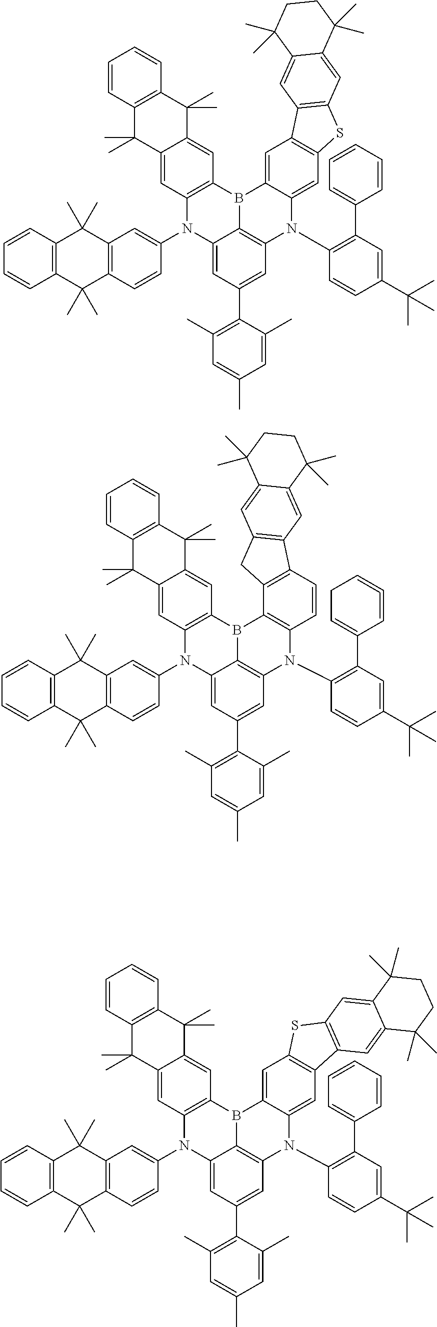

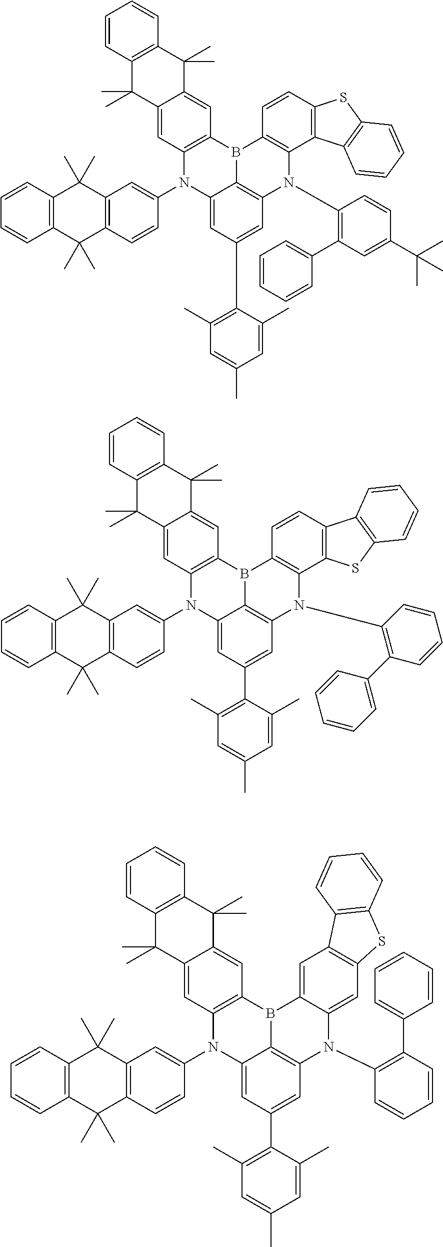 [SMILES: Cc1cc(C)c(-c2cc3c4c(c2)N(c2ccc(C(C)(C)C)cc2-c2ccccc2)c2c(ccc5sc6ccccc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccccc25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5sc6ccccc6c5cc2B4c2cc4c(cc2N3c2ccc3c(c2)C(C)(C)c2ccccc2C3(C)C)C(C)(C)c2ccccc2C4(C)C)c(C)c1]

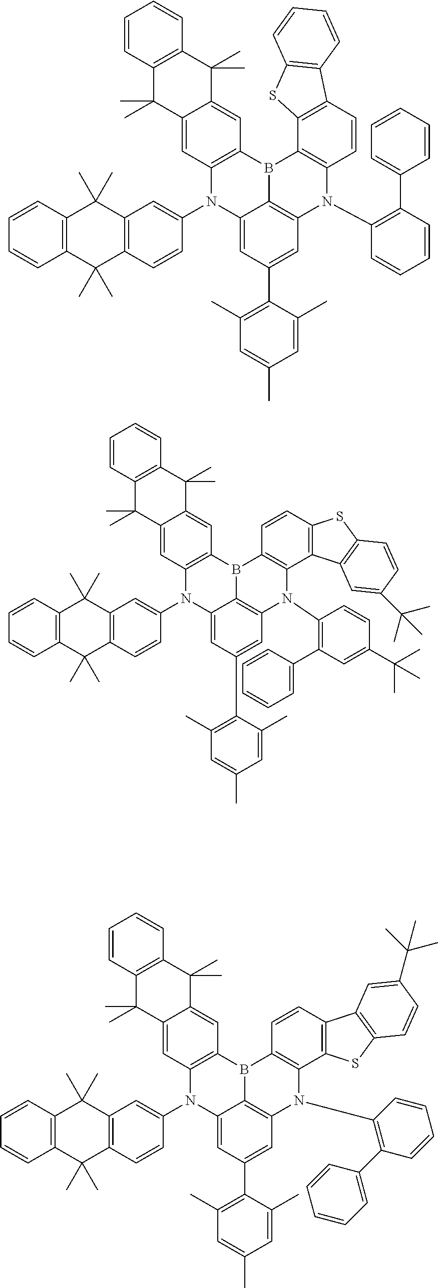 [SMILES: Cc1cc(C)c(-c2cc3c4c(c2)N(c2ccccc2-c2ccccc2)c2ccc5c(sc6ccccc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2ccc3c(c2)C(C)(C)c2ccccc2C3(C)C)C(C)(C)c2ccccc2C4(C)C)c(C)c1]

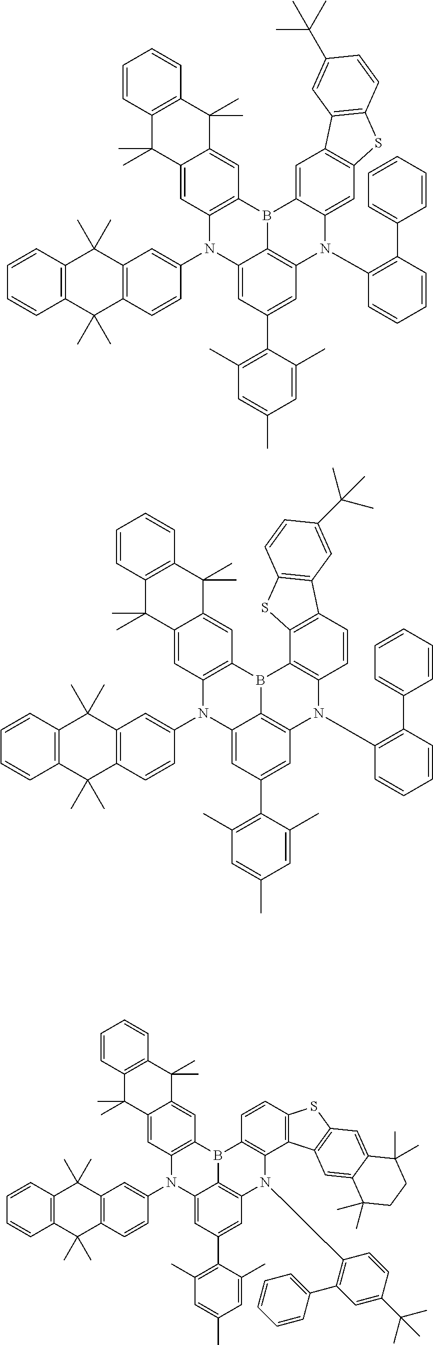 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc3c(c2)C(C)(C)c2ccccc2C3(C)C)C(C)(C)c2ccccc2C4(C)C)c(C)c1]

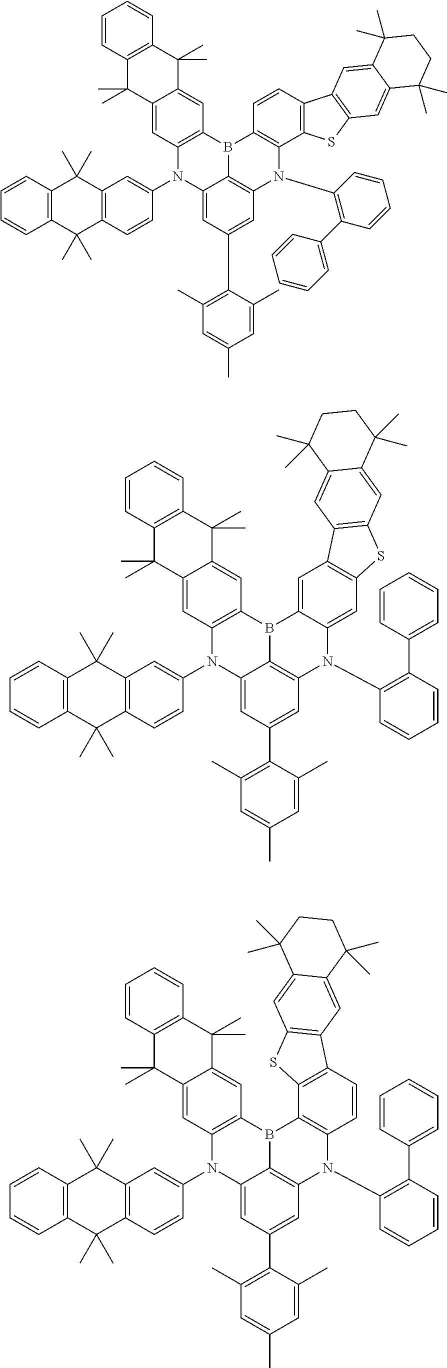 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2ccc3c(c2)C(C)(C)c2ccccc2C3(C)C)C(C)(C)c2ccccc2C4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2ccc3c(c2)C(C)(C)c2ccccc2C3(C)C)C(C)(C)c2ccccc2C4(C)C)c(C)c1]

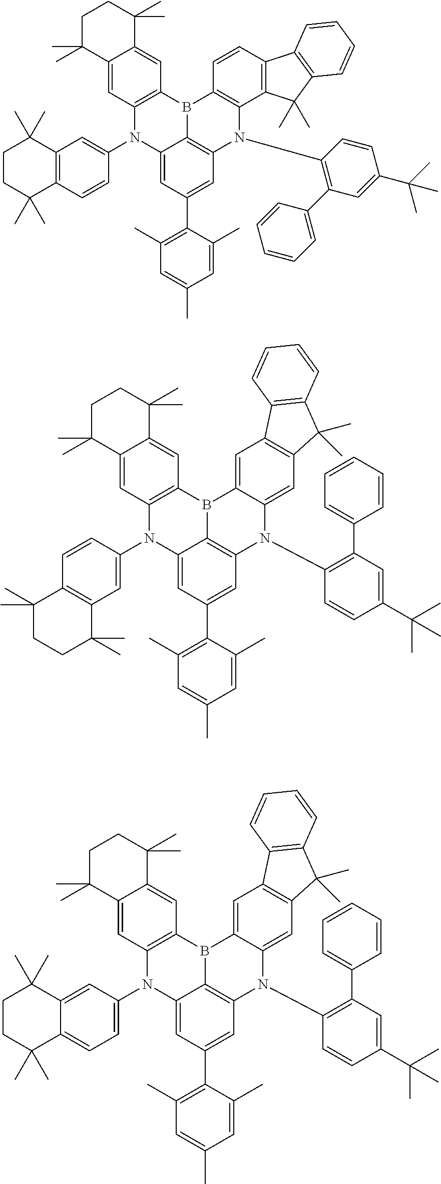

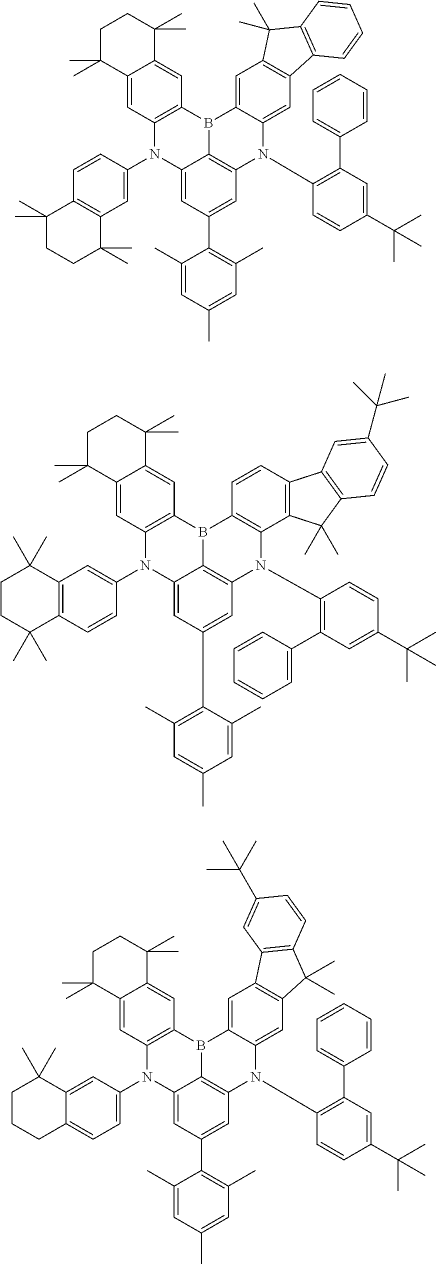

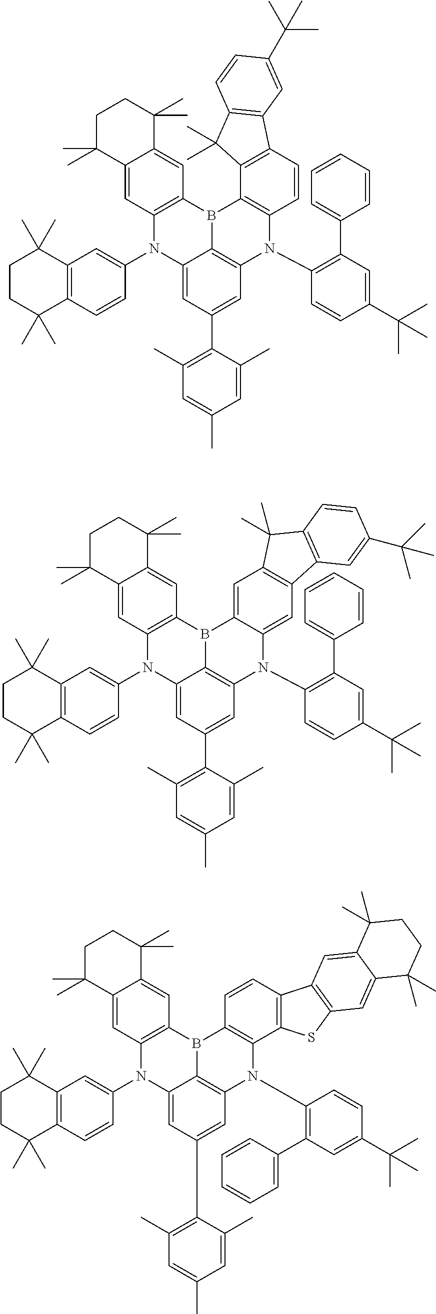 [SMILES: Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c(C)c1]

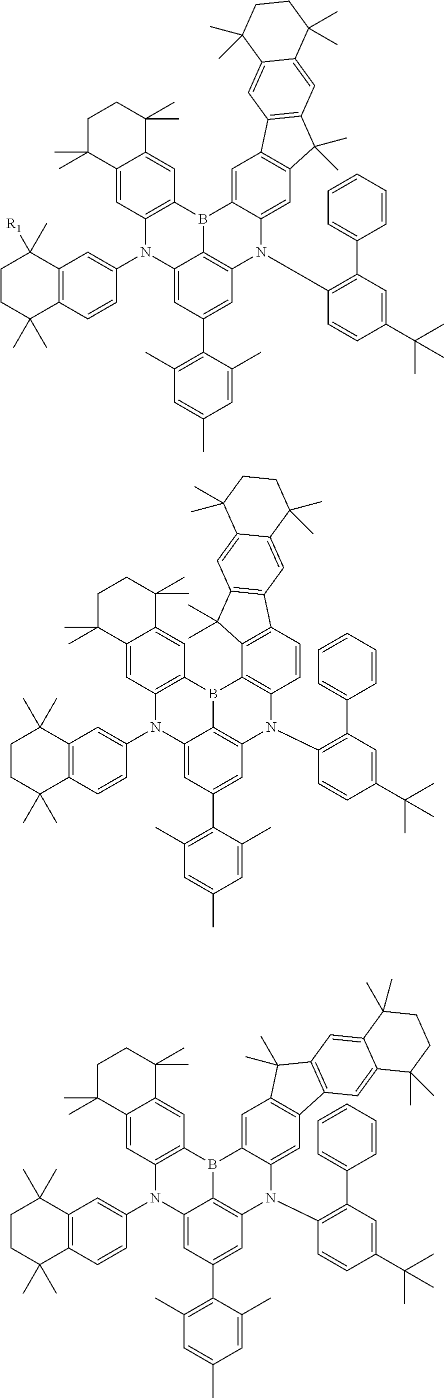

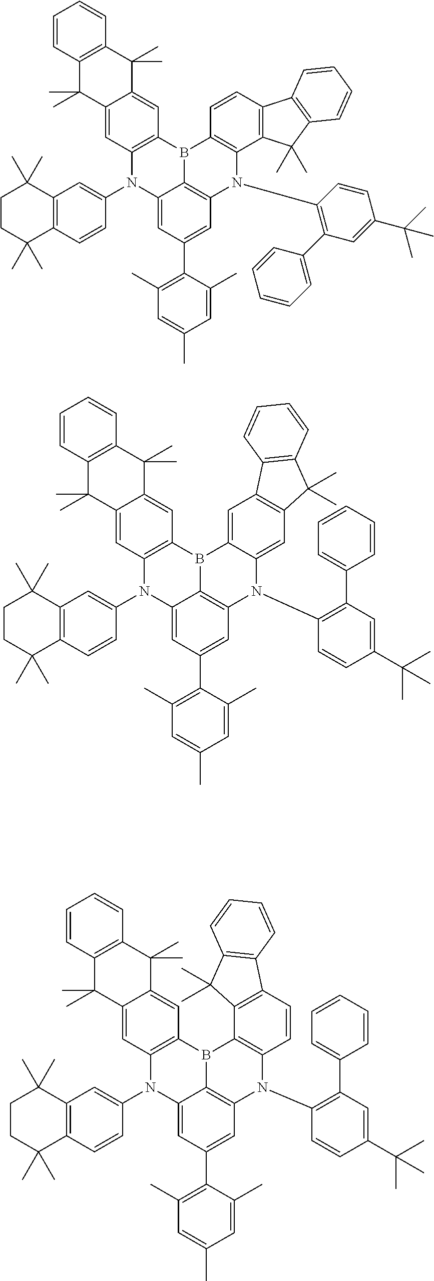 [SMILES: Cc1cc(C)c(-c2cc3c4c(c2)N(c2ccc(C(C)(C)C)cc2-c2ccccc2)c2c(ccc5c2C(C)(C)c2ccccc2-5)B4c2cc4c(cc2N3c2ccc3c(c2)C(C)(C)CCC3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)c2ccccc2C4(C)C)-c2ccccc2C5(C)C)c(C)c1 ; Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)CCC3(C)C)C(C)(C)c2ccccc2C4(C)C)C(C)(C)c2ccccc2-5)c(C)c1]

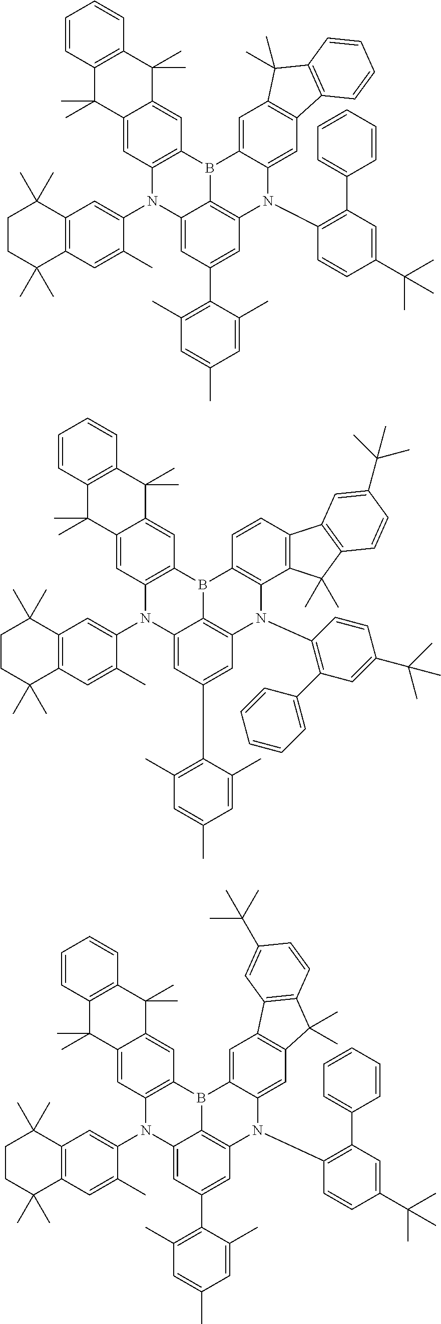

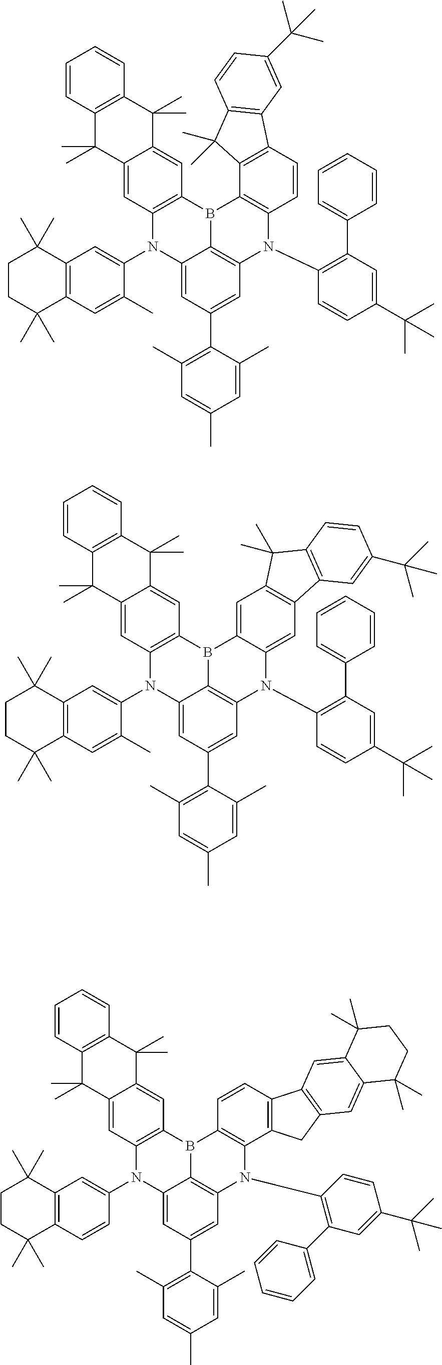 [SMILES: Cc1cc(C)c(-c2cc3c4c(c2)N(c2ccc(C(C)(C)C)cc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2Cc2cc6c(cc2-5)C(C)(C)CCC6(C)C)B4c2cc4c(cc2N3c2ccc3c(c2)C(C)(C)CCC3(C)C)C(C)(C)c2ccccc2C4(C)C)c(C)c1]

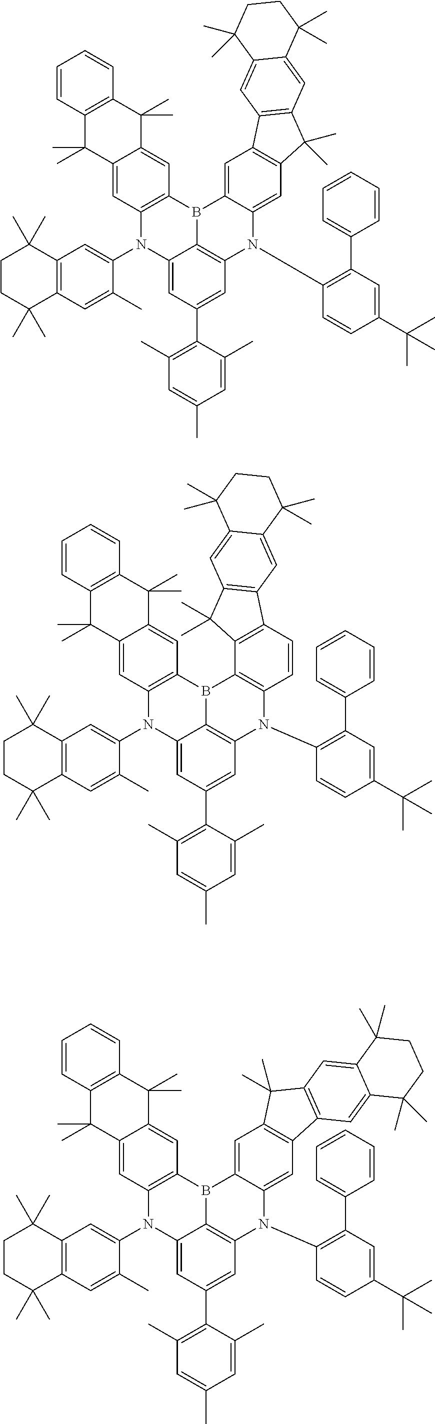

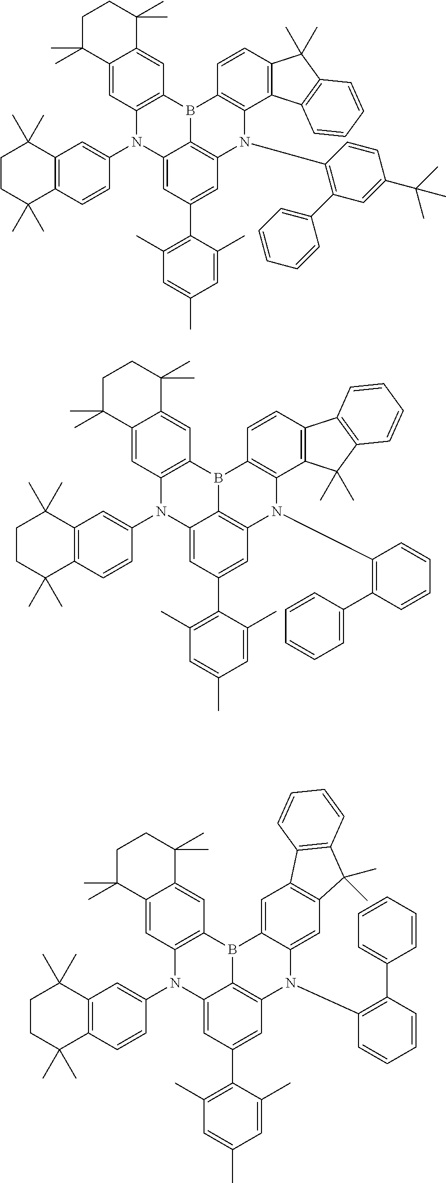

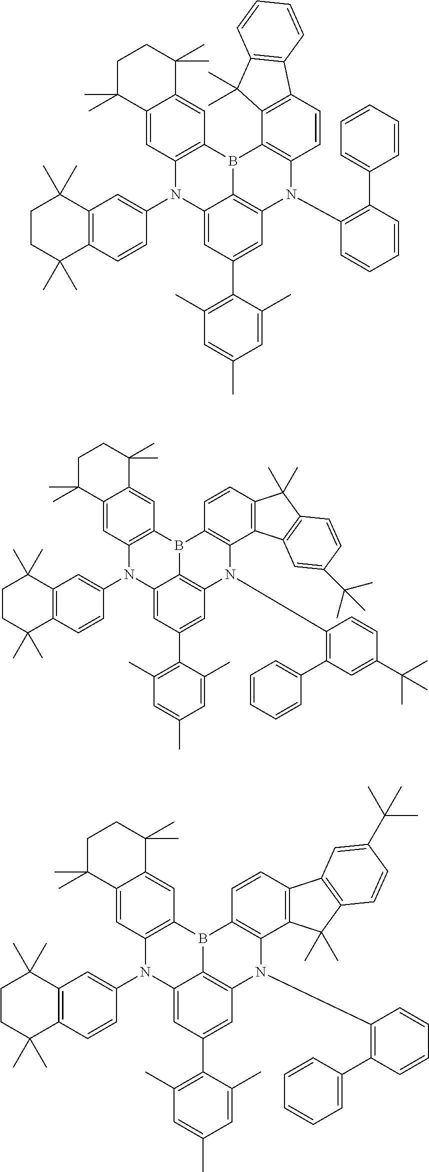 [SMILES: Cc1cc(C)c(-c2cc3c4c(c2)N(c2ccccc2-c2ccccc2)c2ccc5c(c2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccc(C(C)(C)C)cc2-c2ccccc2)c2c(ccc5c2-c2cc(C(C)(C)C)ccc2C5(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2-c2ccccc2)c2c(ccc5c2C(C)(C)c2ccc(C(C)(C)C)cc2-5)B4c2cc4c(cc2N3c2ccc3c(c2)C(C)(C)CCC3(C)C)C(C)(C)CCC4(C)C)c(C)c1]

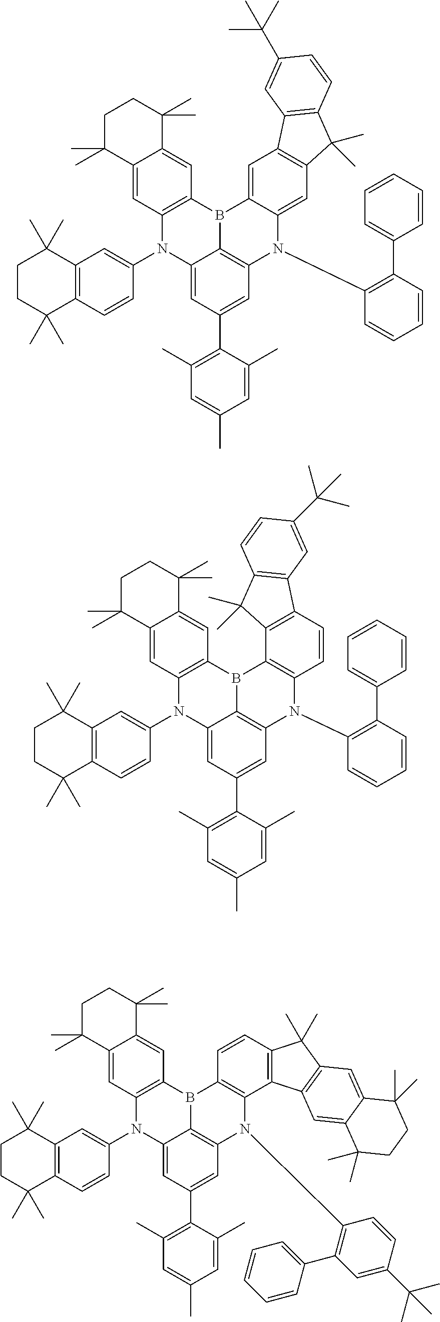 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)-c2cc(C(C)(C)C)ccc2C5(C)C)c(C)c1 ; Cc1cc(C)c(-c2cc3c4c(c2)N(c2ccccc2-c2ccccc2)c2ccc5c(c2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2-c2cc6c(cc2C5(C)C)C(C)(C)CCC6(C)C)B4c2cc4c(cc2N3c2ccc3c(c2)C(C)(C)CCC3(C)C)C(C)(C)CCC4(C)C)c(C)c1]

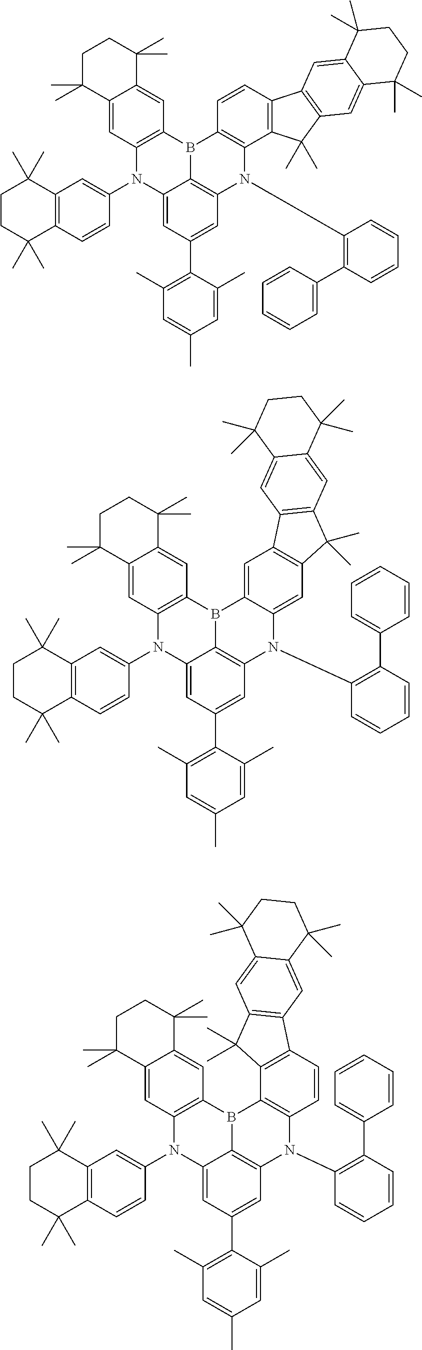

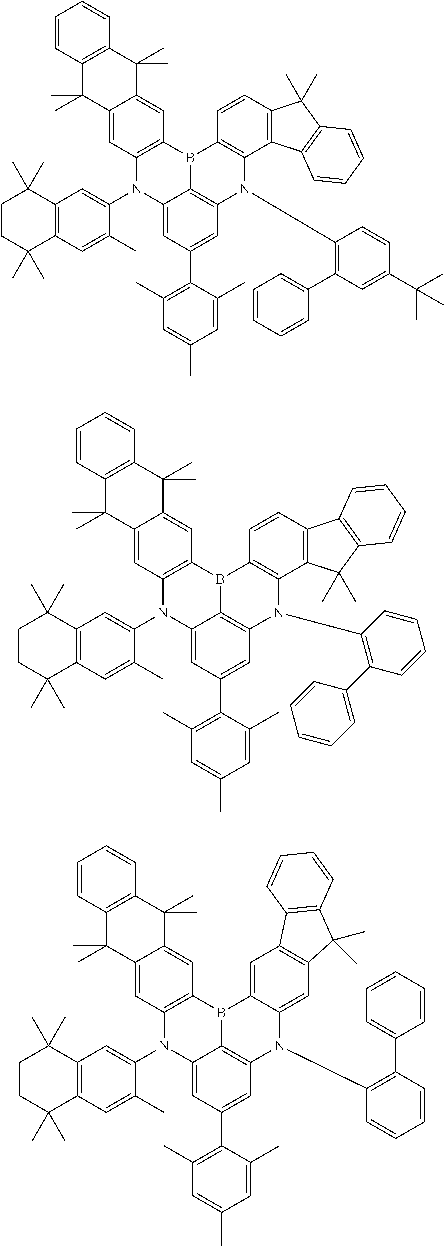 [SMILES: Cc1cc(C)c(-c2cc3c4c(c2)N(c2ccc(C(C)(C)C)cc2-c2ccccc2)c2c(ccc5c2-c2ccccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2C(C)(C)c2ccccc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)-c2ccccc2C5(C)C)c(C)c1]

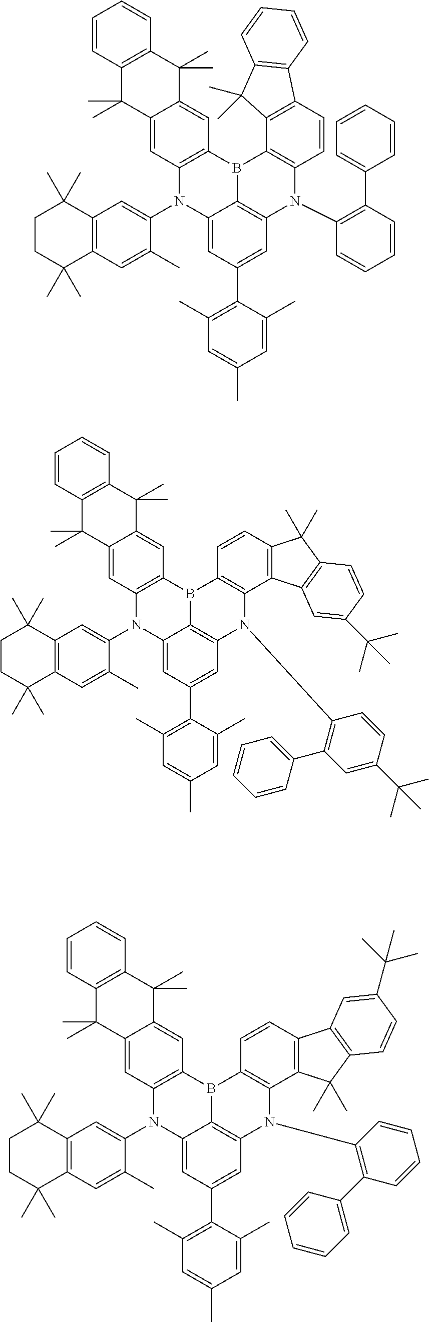 [SMILES: Cc1cc(C)c(-c2cc3c4c(c2)N(c2ccccc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2ccccc2-5)c(C)c1 ; Cc1cc(C)c(-c2cc3c4c(c2)N(c2ccc(C(C)(C)C)cc2-c2ccccc2)c2c(ccc5c2-c2cc(C(C)(C)C)ccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2c(ccc5c2C(C)(C)c2ccc(C(C)(C)C)cc2-5)B4c2cc4c(cc2N3c2cc3c(cc2C)C(C)(C)CCC3(C)C)C(C)(C)c2ccccc2C4(C)C)c(C)c1]

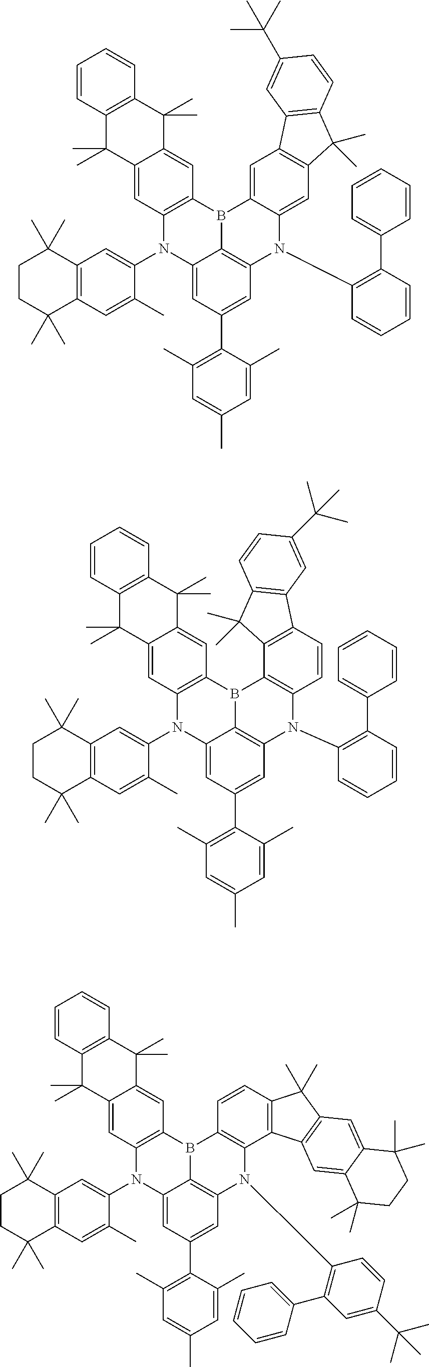 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)-c2cc(C(C)(C)C)ccc2C5(C)C)c(C)c1 ; Cc1cc(C)c(-c2cc3c4c(c2)N(c2ccccc2-c2ccccc2)c2ccc5c(c2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2-c2cc6c(cc2C5(C)C)C(C)(C)CCC6(C)C)B4c2cc4c(cc2N3c2cc3c(cc2C)C(C)(C)CCC3(C)C)C(C)(C)c2ccccc2C4(C)C)c(C)c1]

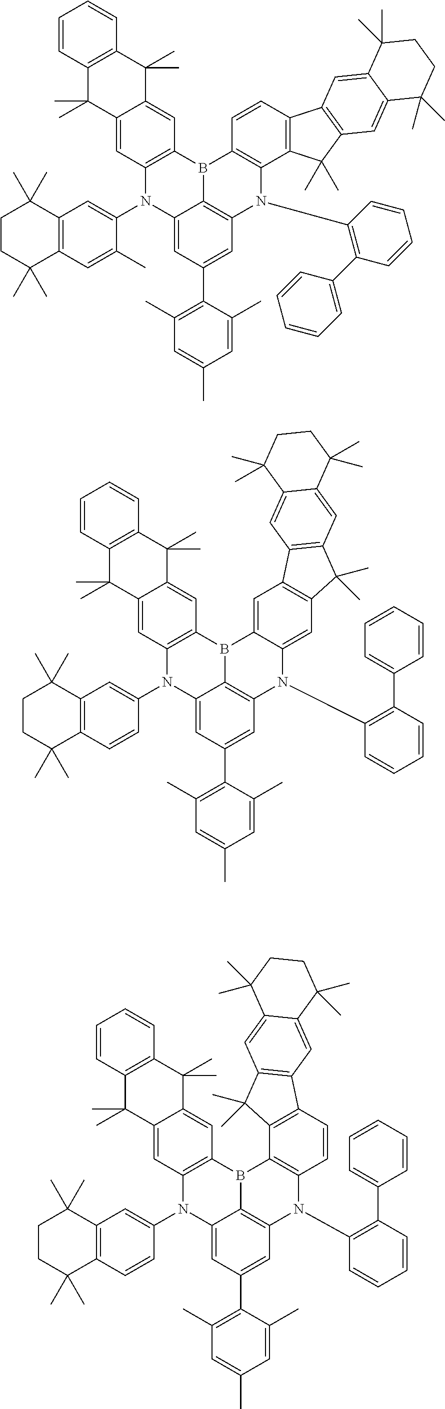 [SMILES: Cc1cc(C)c(-c2cc3c4c(c2)N(c2ccccc2-c2ccccc2)c2c(ccc5c2C(C)(C)c2cc6c(cc2-5)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)c2ccccc2C4(C)C)-c2cc3c(cc2C5(C)C)C(C)(C)CCC3(C)C)c(C)c1 ; Cc1cc(C)c(-c2cc3c4c(c2)N(c2ccccc2-c2ccccc2)c2ccc5c(c2B4c2cc4c(cc2N3c2ccc3c(c2)C(C)(C)CCC3(C)C)C(C)(C)c2ccccc2C4(C)C)C(C)(C)c2cc3c(cc2-5)C(C)(C)CCC3(C)C)c(C)c1]

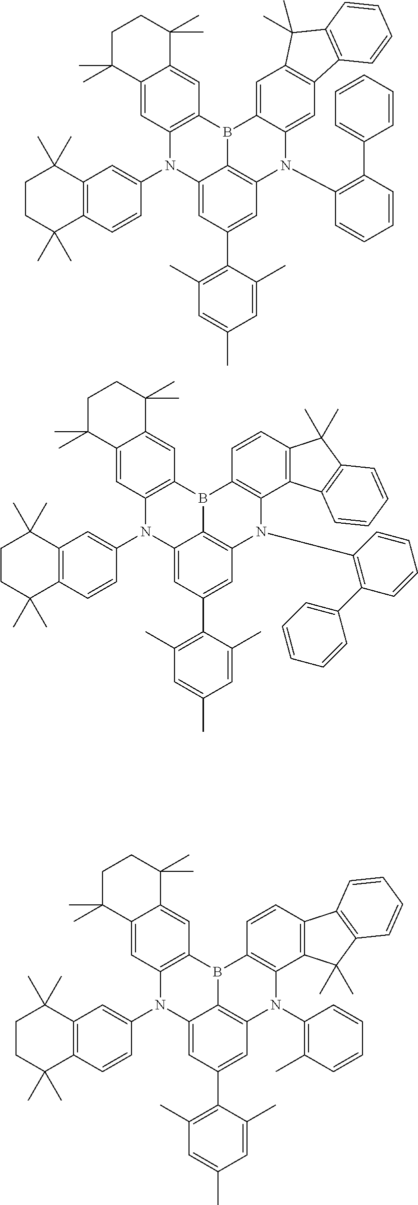 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccccc2-c2ccccc2)c2c(ccc5c2-c2ccccc2C5(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2c(ccc5c2C(C)(C)c2ccccc2-5)B4c2cc4c(cc2N3c2ccc3c(c2)C(C)(C)CCC3(C)C)C(C)(C)CCC4(C)C)c(C)c1]

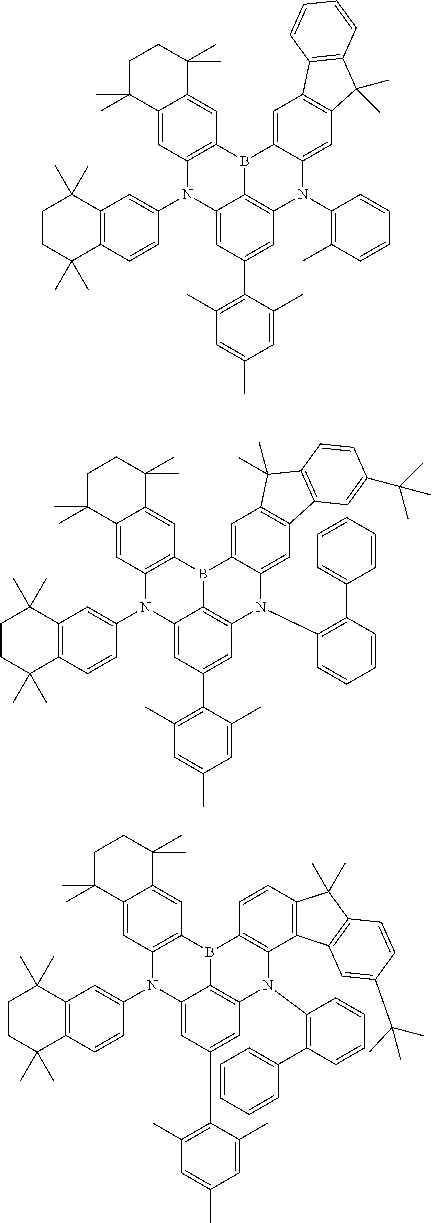

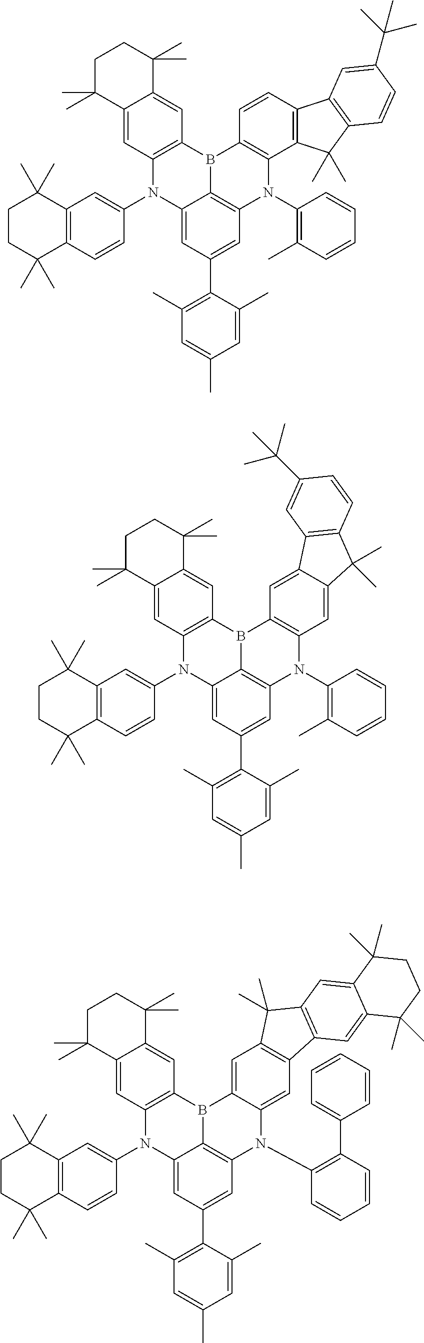 [SMILES: Cc1cc(C)c(-c2cc3c4c(c2)N(c2ccccc2C)c2c(ccc5c2C(C)(C)c2ccc(C(C)(C)C)cc2-5)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)-c2cc(C(C)(C)C)ccc2C5(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1]

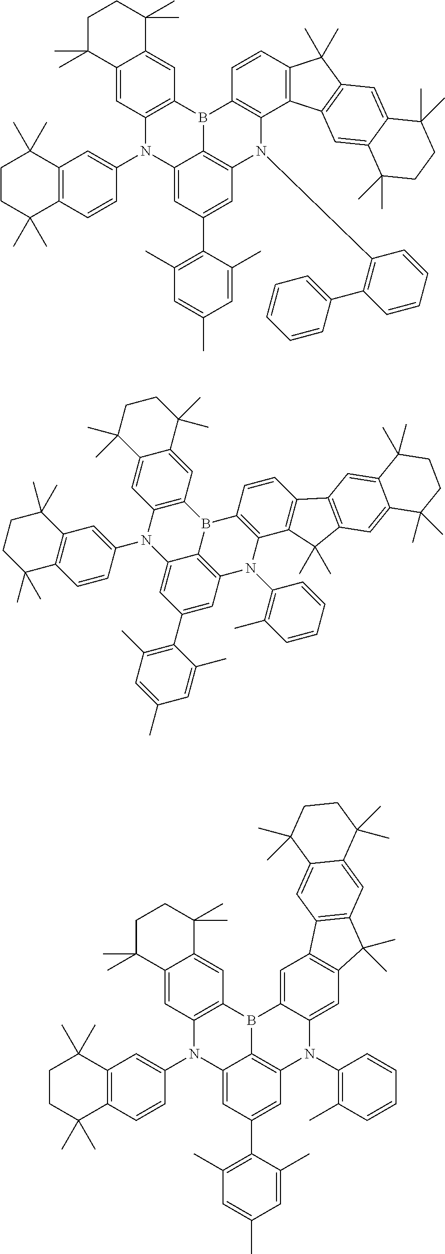

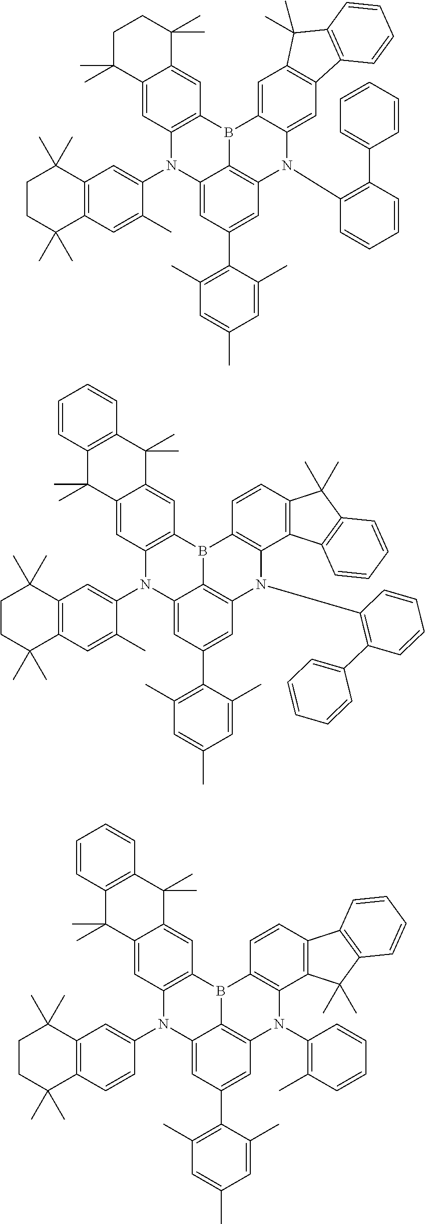 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CCC4(C)C)C(C)(C)c2ccccc2-5)c(C)c1 ; Cc1cc(C)c(-c2cc3c4c(c2)N(c2ccccc2-c2ccccc2)c2c(ccc5c2-c2ccccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2c(ccc5c2C(C)(C)c2ccccc2-5)B4c2cc4c(cc2N3c2ccc3c(c2)C(C)(C)CCC3(C)C)C(C)(C)c2ccccc2C4(C)C)c(C)c1]

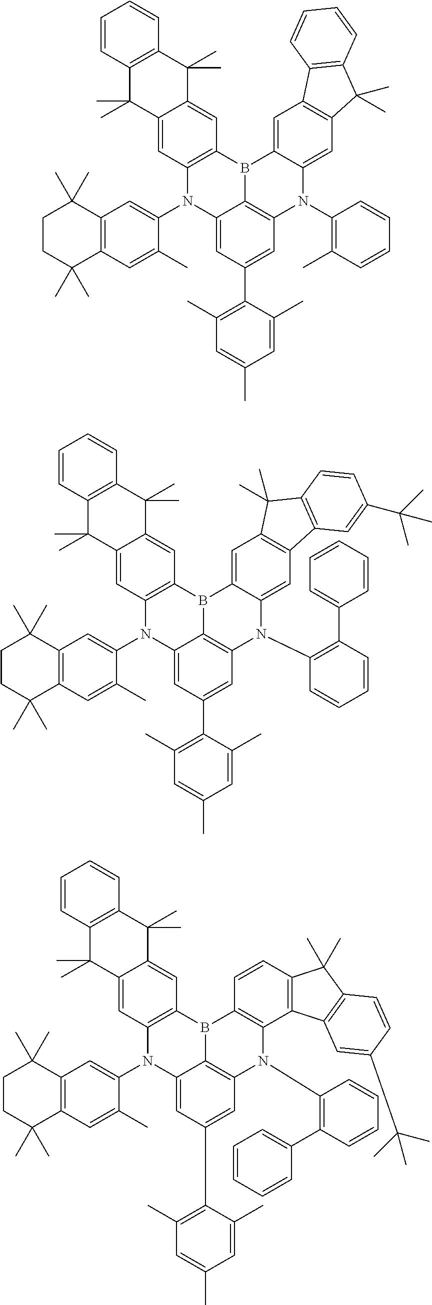 [SMILES: Cc1cc(C)c(-c2cc3c4c(c2)N(c2cc5c(cc2C)C(C)(C)CCC5(C)C)c2cc5c(cc2B4c2cc4c(cc2N3c2ccccc2C)C(C)(C)c2ccccc2-4)C(C)(C)c2ccccc2C5(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccccc2-c2ccccc2)c2c(ccc5c2-c2cc(C(C)(C)C)ccc2C5(C)C)B4c2cc4c(cc2N3c2cc3c(cc2C)C(C)(C)CCC3(C)C)C(C)(C)c2ccccc2C4(C)C)c(C)c1]

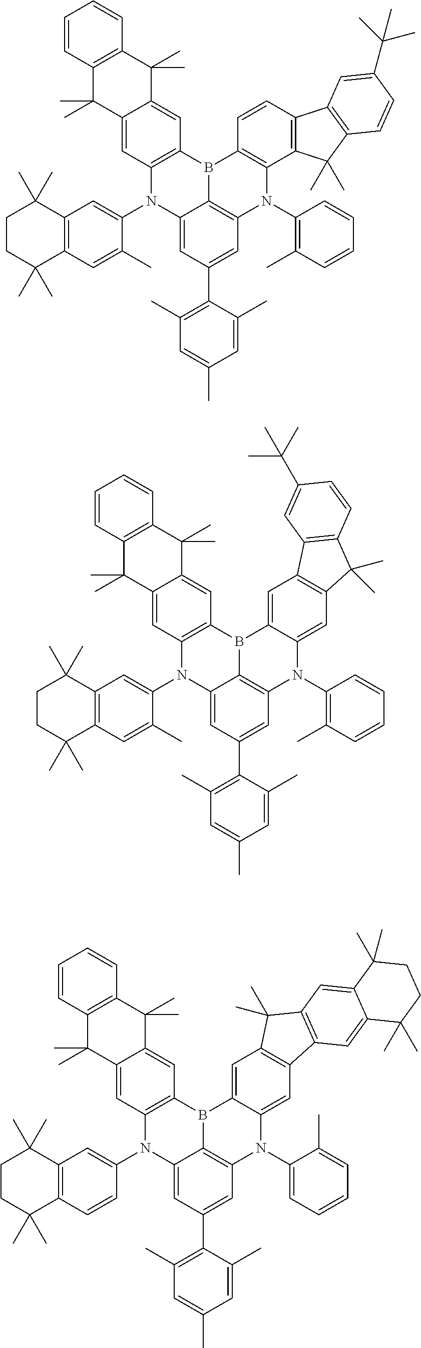 [SMILES: Cc1cc(C)c(-c2cc3c4c(c2)N(c2ccccc2C)c2c(ccc5c2C(C)(C)c2ccc(C(C)(C)C)cc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccccc2C)C(C)(C)c2ccc(C(C)(C)C)cc2-4)C(C)(C)c2ccccc2C5(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)c2ccccc2C4(C)C)C(C)(C)c2cc3c(cc2-5)C(C)(C)CCC3(C)C)c(C)c1]

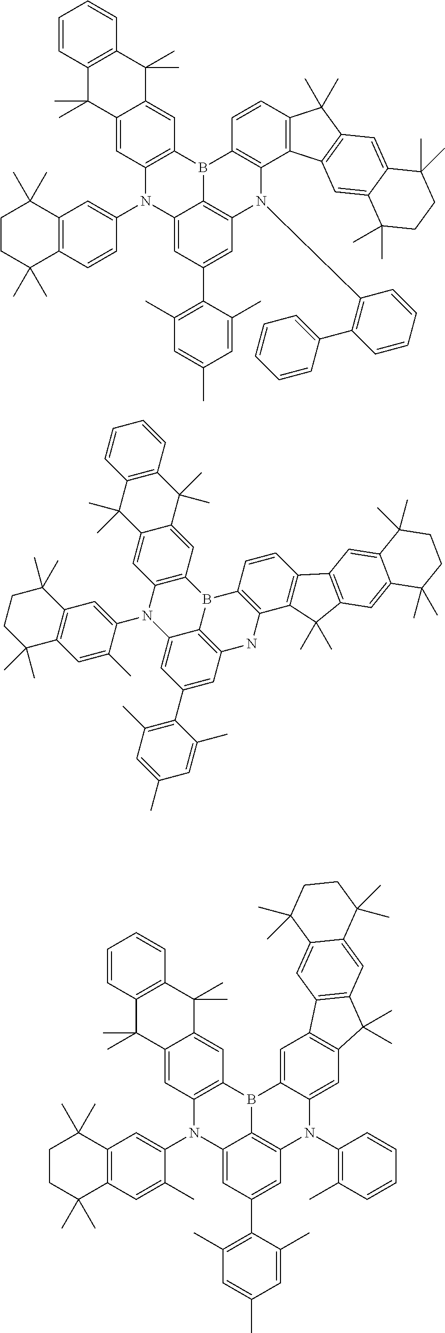 [SMILES: Cc1cc(C)c(-c2cc3c4c(c2)N(c2ccccc2-c2ccccc2)c2c(ccc5c2-c2cc6c(cc2C5(C)C)C(C)(C)CCC6(C)C)B4c2cc4c(cc2N3c2ccc3c(c2)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2ccc4c(c2N3)C(C)(C)c2cc3c(cc2-4)C(C)(C)CCC3(C)C)C(C)(C)c2ccccc2C5(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccccc2C)C(C)(C)c2cc3c(cc2-4)C(C)(C)CCC3(C)C)C(C)(C)c2ccccc2C5(C)C)c(C)c1]

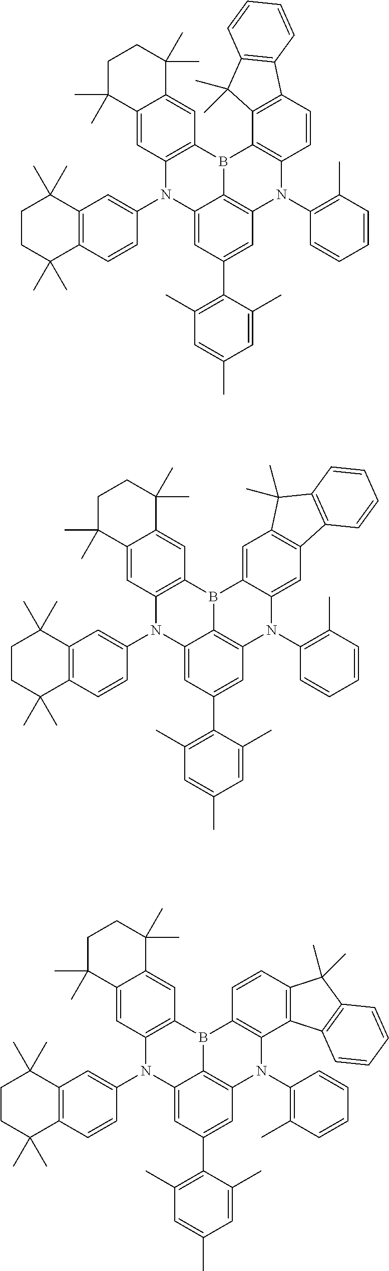 [SMILES: Cc1cc(C)c(-c2cc3c4c(c2)N(c2ccccc2C)c2ccc5c(c2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)C(C)(C)c2ccccc2-5)c(C)c1 ; Cc1cc(C)c(-c2cc3c4c(c2)N(c2ccccc2C)c2c(ccc5c2-c2ccccc2C5(C)C)B4c2cc4c(cc2N3c2ccc3c(c2)C(C)(C)CCC3(C)C)C(C)(C)CCC4(C)C)c(C)c1]

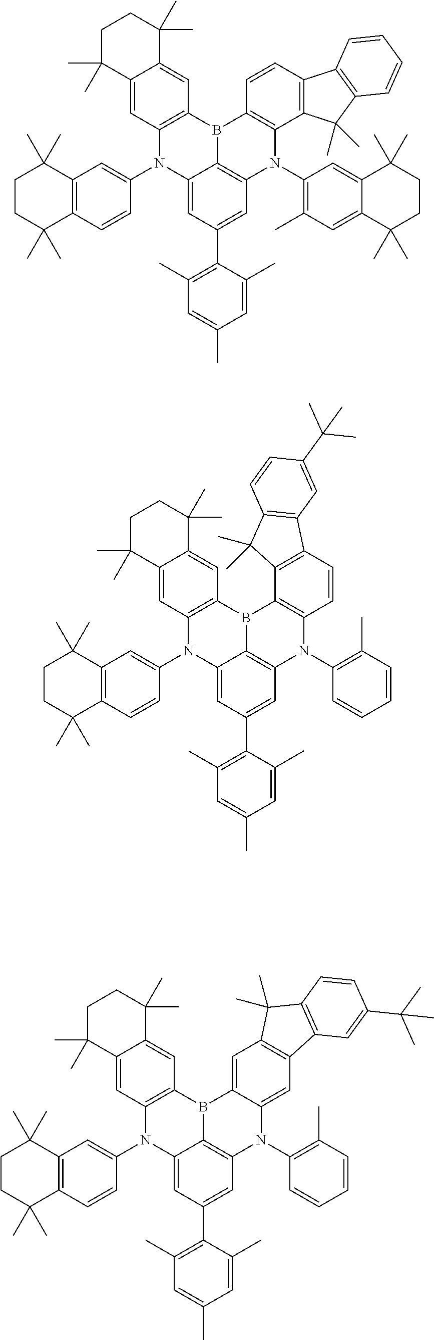 [SMILES: Cc1cc(C)c(-c2cc3c4c(c2)N(c2cc5c(cc2C)C(C)(C)CCC5(C)C)c2c(ccc5c2C(C)(C)c2ccccc2-5)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccccc2C)c2ccc5c(c2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1 ; Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)C(C)(C)c2ccc(C(C)(C)C)cc2-5)c(C)c1]

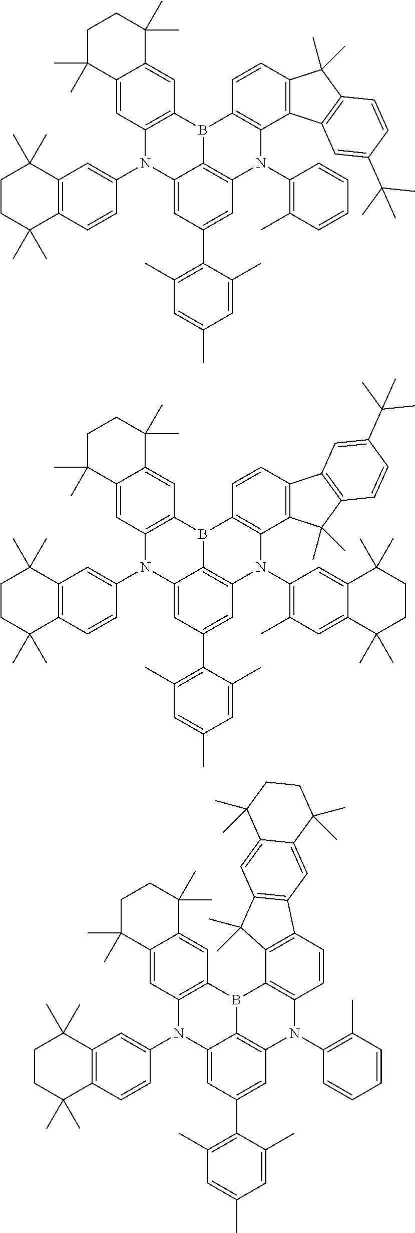

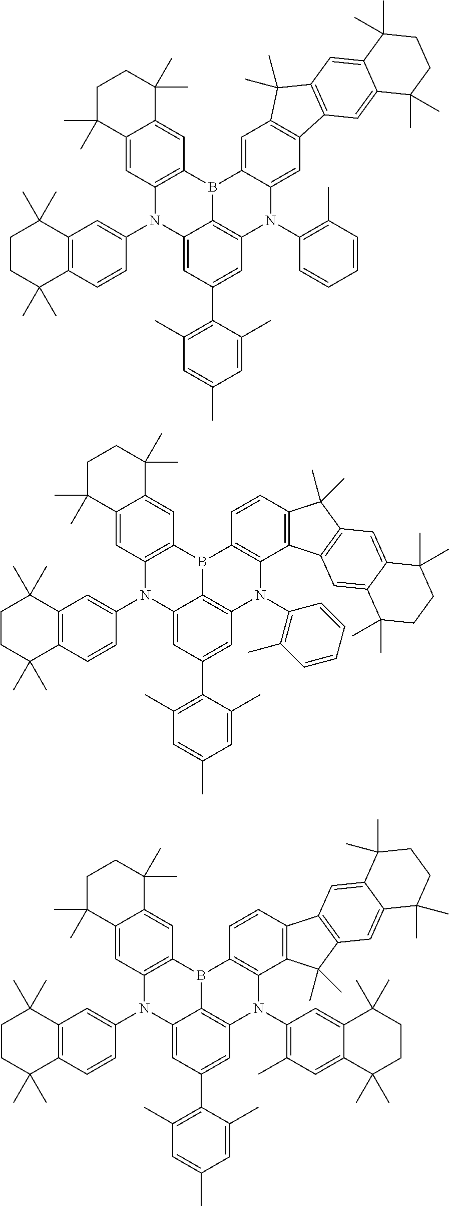 [SMILES: Cc1cc(C)c(-c2cc3c4c(c2)N(c2ccccc2C)c2cc5c(cc2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1 ; Cc1cc(C)c(-c2cc3c4c(c2)N(c2ccccc2C)c2c(ccc5c2-c2cc6c(cc2C5(C)C)C(C)(C)CCC6(C)C)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5c2C(C)(C)c2cc6c(cc2-5)C(C)(C)CCC6(C)C)B4c2cc4c(cc2N3c2ccc3c(c2)C(C)(C)CCC3(C)C)C(C)(C)CCC4(C)C)c(C)c1]

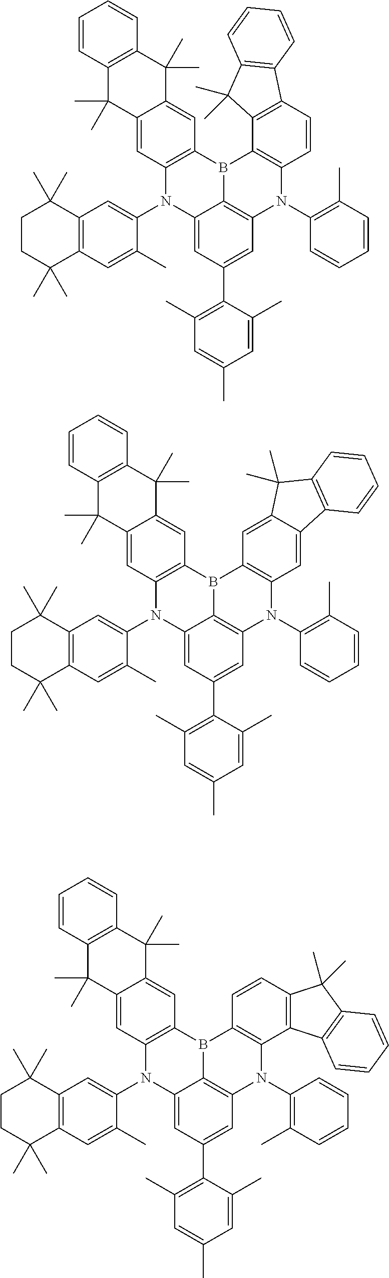 [SMILES: Cc1cc(C)c(-c2cc3c4c(c2)N(c2ccccc2C)c2ccc5c(c2B4c2cc4c(cc2N3c2cc3c(cc2C)C(C)(C)CCC3(C)C)C(C)(C)c2ccccc2C4(C)C)C(C)(C)c2ccccc2-5)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccccc2C)-c2ccccc2C4(C)C)C(C)(C)c2ccccc2C5(C)C)c(C)c1 ; Cc1cc(C)c(-c2cc3c4c(c2)N(c2ccccc2C)c2c(ccc5c2-c2ccccc2C5(C)C)B4c2cc4c(cc2N3c2cc3c(cc2C)C(C)(C)CCC3(C)C)C(C)(C)c2ccccc2C4(C)C)c(C)c1]

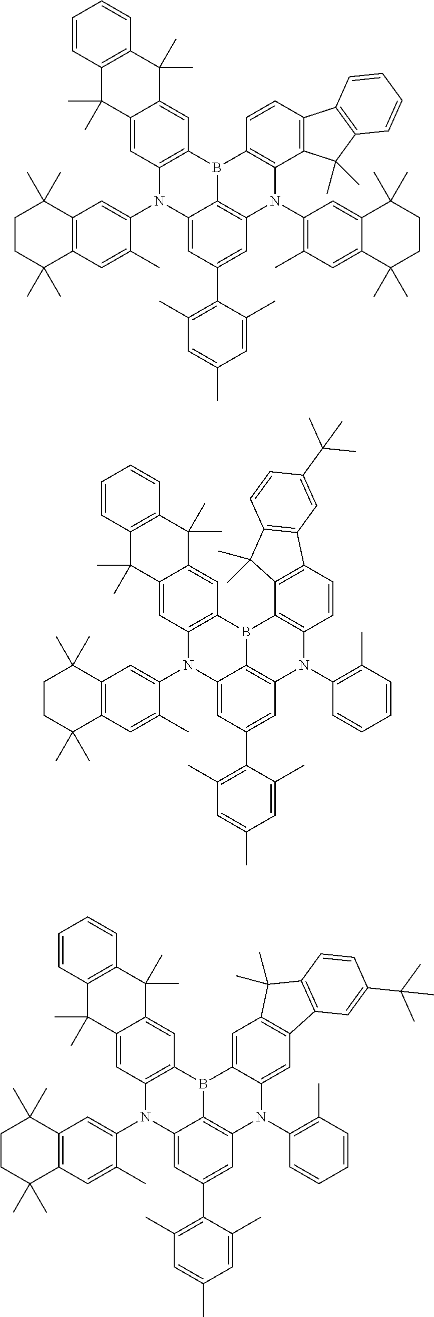 [SMILES: Cc1cc(C)c(-c2cc3c4c(c2)N(c2cc5c(cc2C)C(C)(C)CCC5(C)C)c2c(ccc5c2C(C)(C)c2ccccc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(c2B4c2cc4c(cc2N3c2cc3c(cc2C)C(C)(C)CCC3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccccc2C)-c2cc(C(C)(C)C)ccc2C4(C)C)C(C)(C)c2ccccc2C5(C)C)c(C)c1]

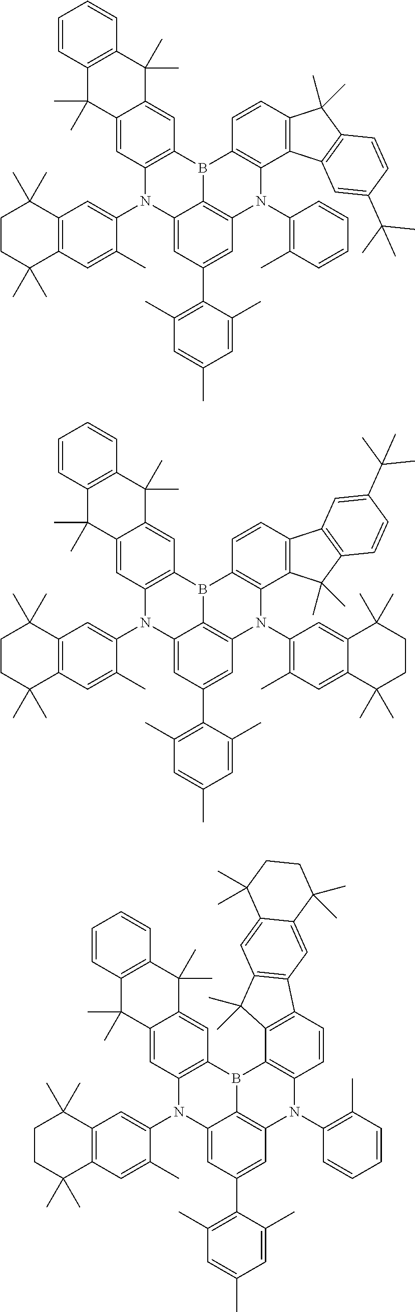 [SMILES: Cc1cc(C)c(-c2cc3c4c(c2)N(c2ccccc2C)c2c(ccc5c2-c2cc(C(C)(C)C)ccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2C(C)(C)c2ccc(C(C)(C)C)cc2-5)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2ccccc2C)c2ccc5c(c2B4c2cc4c(cc2N3c2cc3c(cc2C)C(C)(C)CCC3(C)C)C(C)(C)c2ccccc2C4(C)C)C(C)(C)c2cc3c(cc2-5)C(C)(C)CCC3(C)C)c(C)c1]

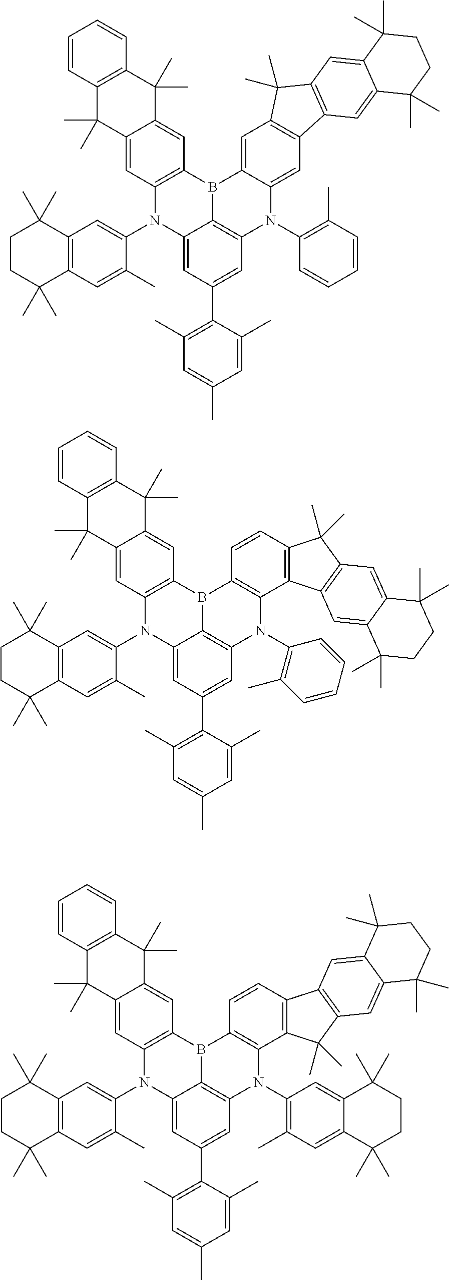 [SMILES: Cc1cc(C)c(-c2cc3c4c(c2)N(c2cc5c(cc2C)C(C)(C)CCC5(C)C)c2cc5c(cc2B4c2cc4c(cc2N3c2ccccc2C)-c2cc3c(cc2C4(C)C)C(C)(C)CCC3(C)C)C(C)(C)c2ccccc2C5(C)C)c(C)c1 ; Cc1cc(C)c(-c2cc3c4c(c2)N(c2ccccc2C)c2c(ccc5c2-c2cc6c(cc2C5(C)C)C(C)(C)CCC6(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2C(C)(C)c2cc6c(cc2-5)C(C)(C)CCC6(C)C)B4c2cc4c(cc2N3c2cc3c(cc2C)C(C)(C)CCC3(C)C)C(C)(C)c2ccccc2C4(C)C)c(C)c1]

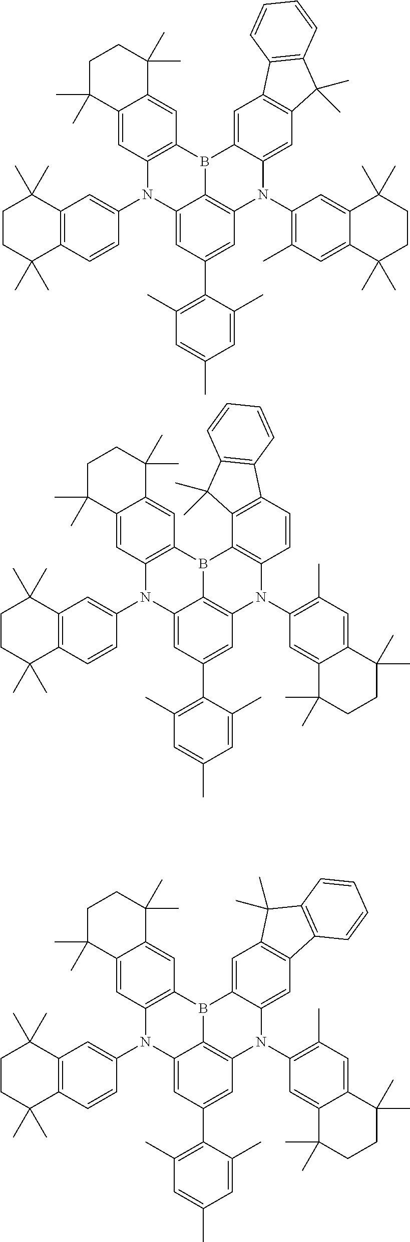

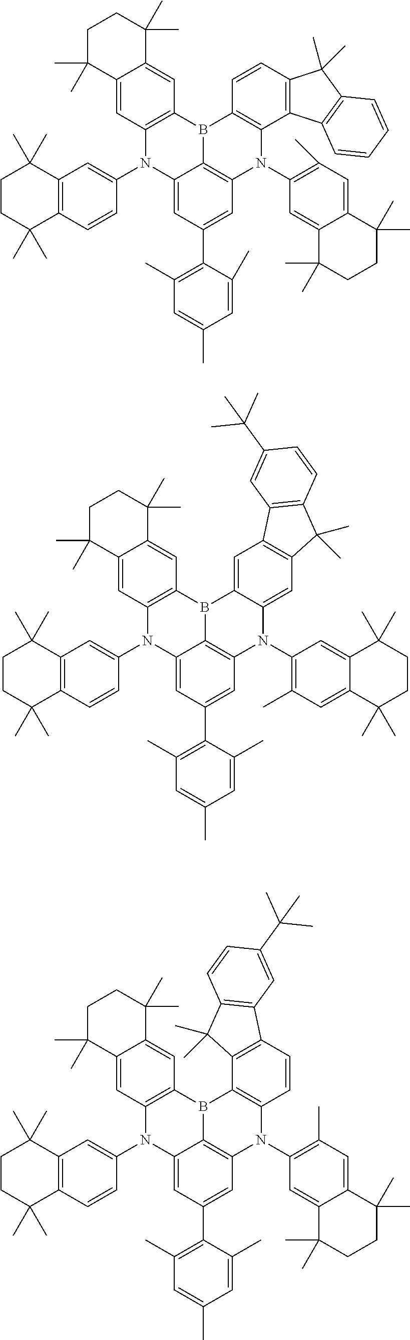

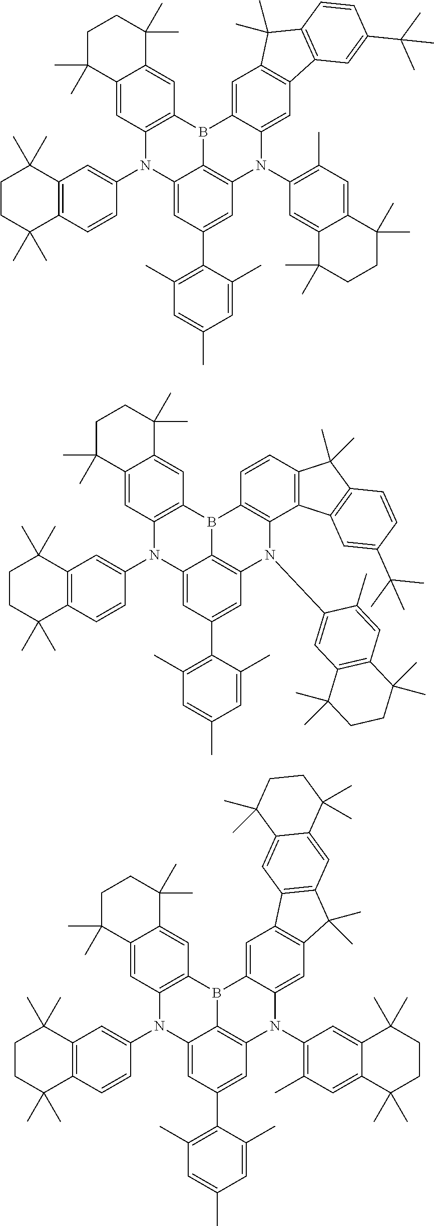

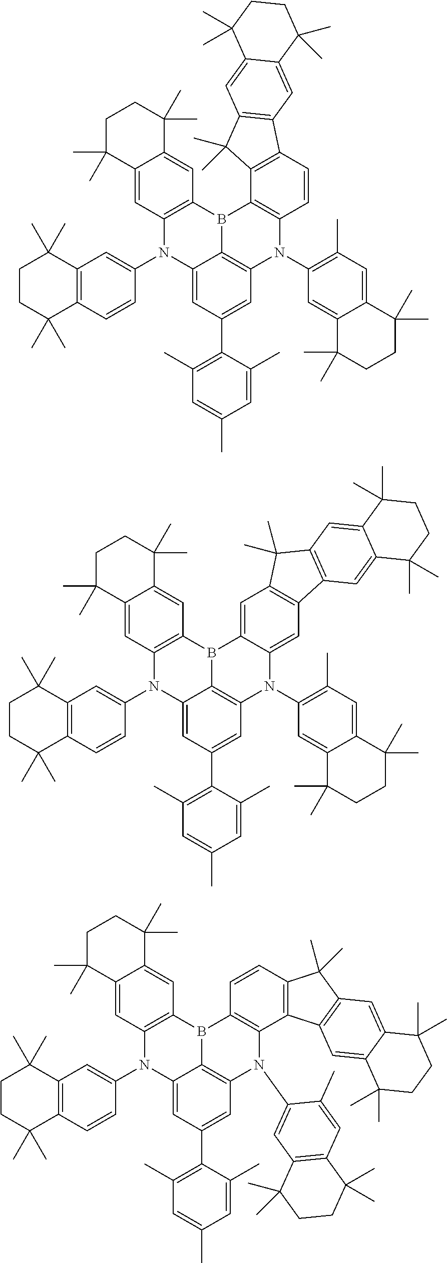 [SMILES: Cc1cc(C)c(-c2cc3c4c(c2)N(c2cc5c(cc2C)C(C)(C)CCC5(C)C)c2ccc5c(c2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2-c2cc6c(cc2C5(C)C)C(C)(C)CCC6(C)C)B4c2cc4c(cc2N3c2ccc3c(c2)C(C)(C)CCC3(C)C)C(C)(C)CCC4(C)C)c(C)c1]

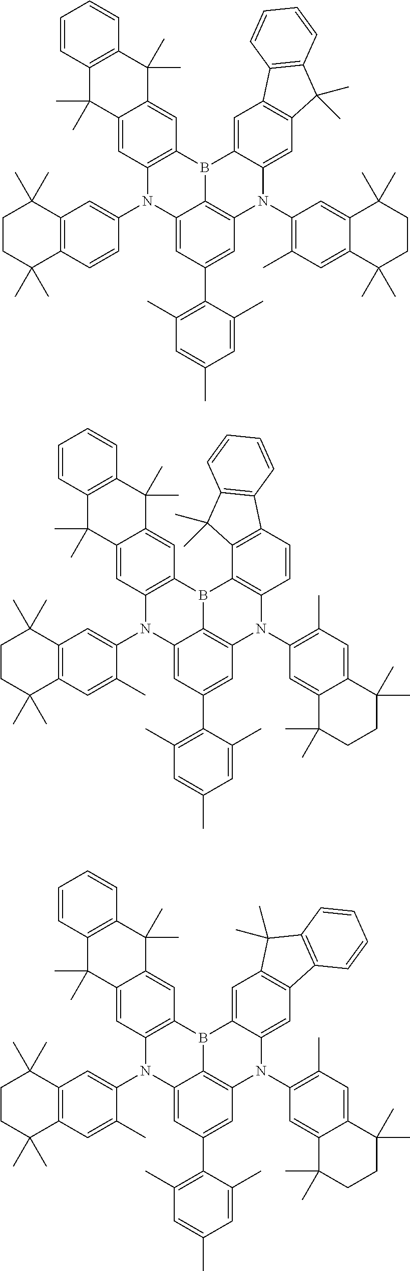

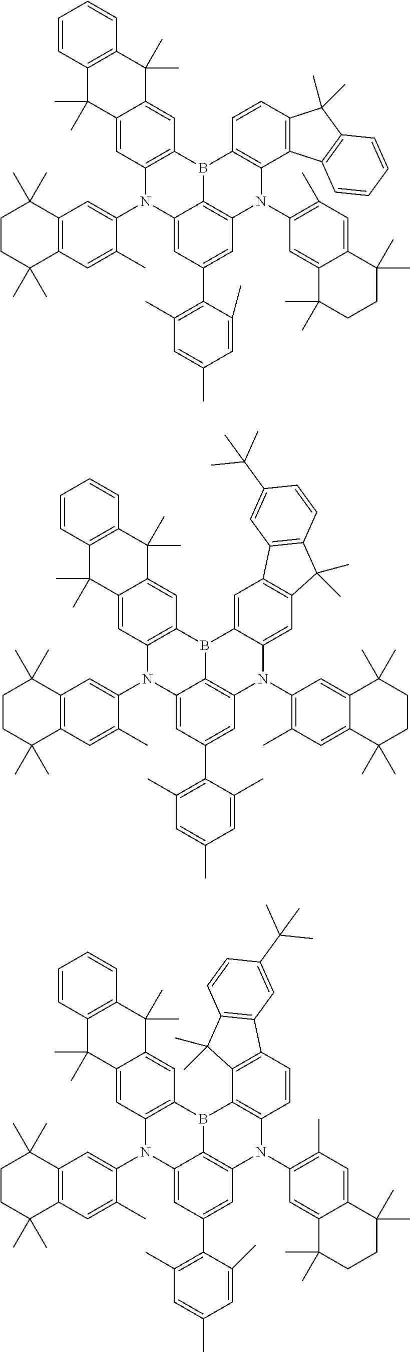

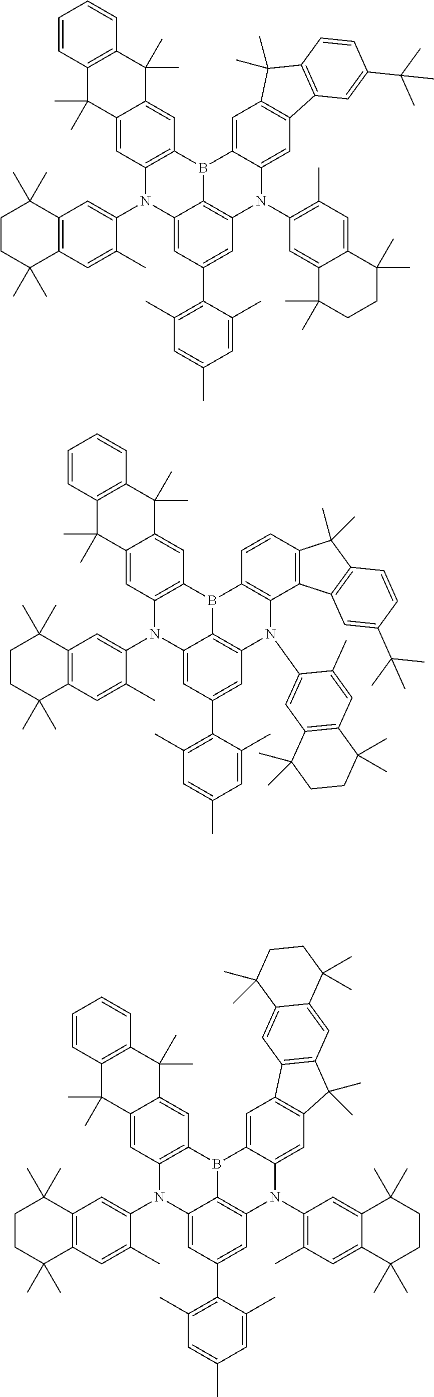 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)-c2cc(C(C)(C)C)ccc2C4(C)C)C(C)(C)c2ccccc2C5(C)C)c(C)c1 ; Cc1cc(C)c(-c2cc3c4c(c2)N(c2cc5c(cc2C)C(C)(C)CCC5(C)C)c2c(ccc5c2-c2cc(C(C)(C)C)ccc2C5(C)C)B4c2cc4c(cc2N3c2cc3c(cc2C)C(C)(C)CCC3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)c2cc3c(cc2-4)C(C)(C)CCC3(C)C)C(C)(C)c2ccccc2C5(C)C)c(C)c1]

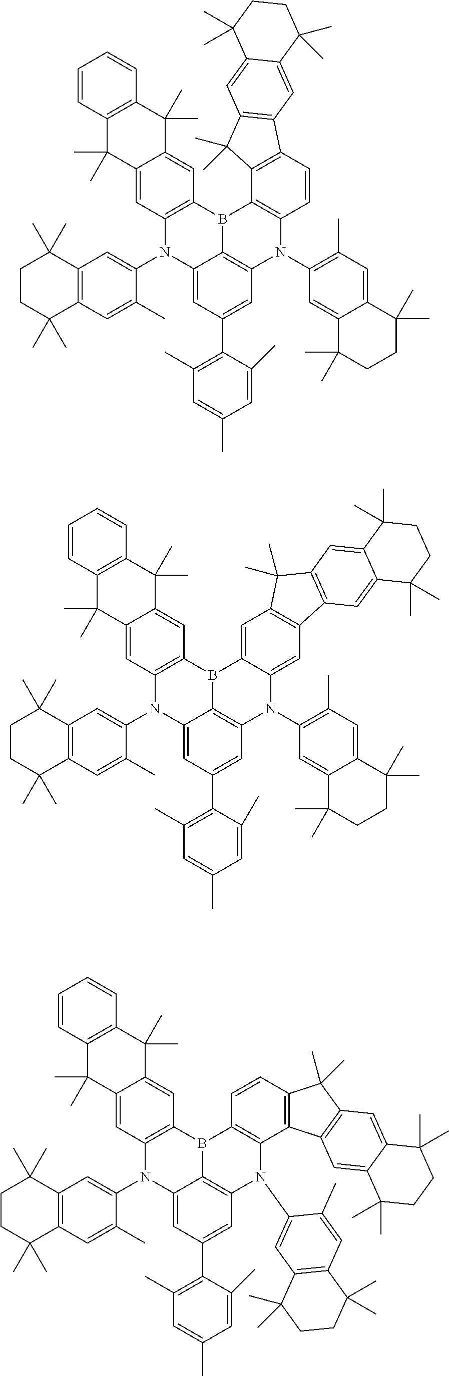

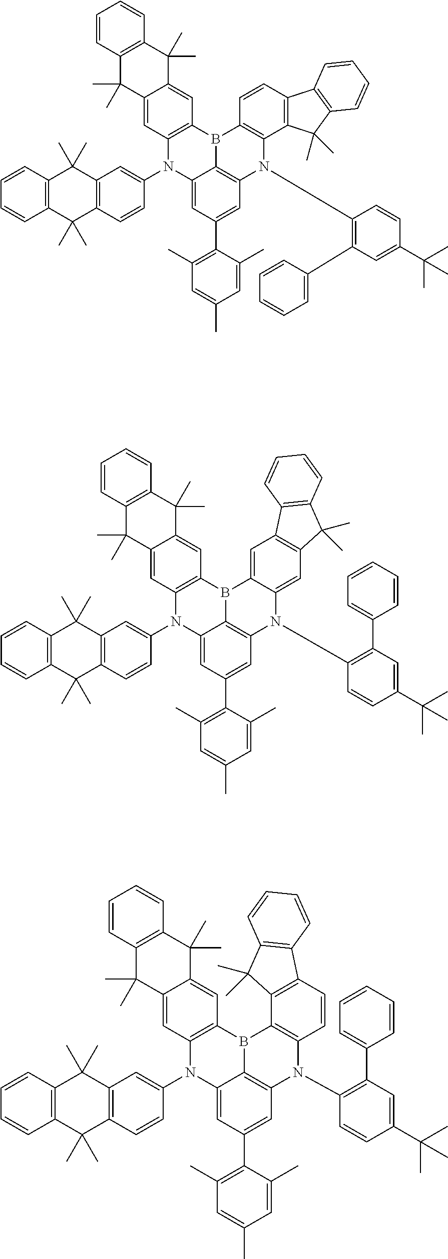 [SMILES: Cc1cc(C)c(-c2cc3c4c(c2)N(c2ccc(C(C)(C)C)cc2-c2ccccc2)c2c(ccc5c2C(C)(C)c2ccccc2-5)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)-c2ccccc2C5(C)C)c(C)c1 ; Cc1cc(C)c(-c2cc3c4c(c2)N(c2ccc(C(C)(C)C)cc2-c2ccccc2)c2ccc5c(c2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1]

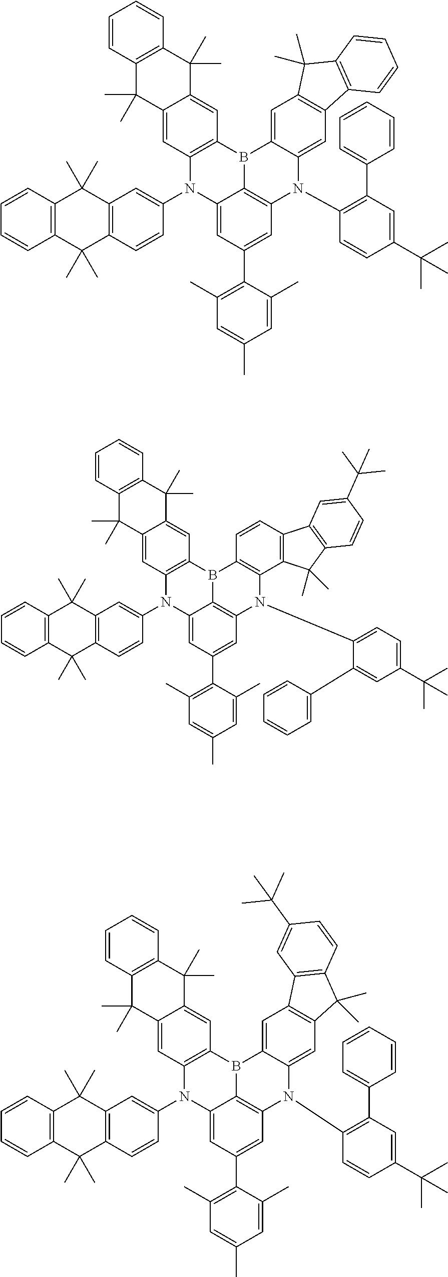 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1 ; Cc1cc(C)c(-c2cc3c4c(c2)N(c2ccc(C(C)(C)C)cc2-c2ccccc2)c2c(ccc5c2C(C)(C)c2ccc(C(C)(C)C)cc2-5)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)c2ccccc2C3(C)C)C(C)(C)c2ccccc2C4(C)C)-c2cc(C(C)(C)C)ccc2C5(C)C)c(C)c1]

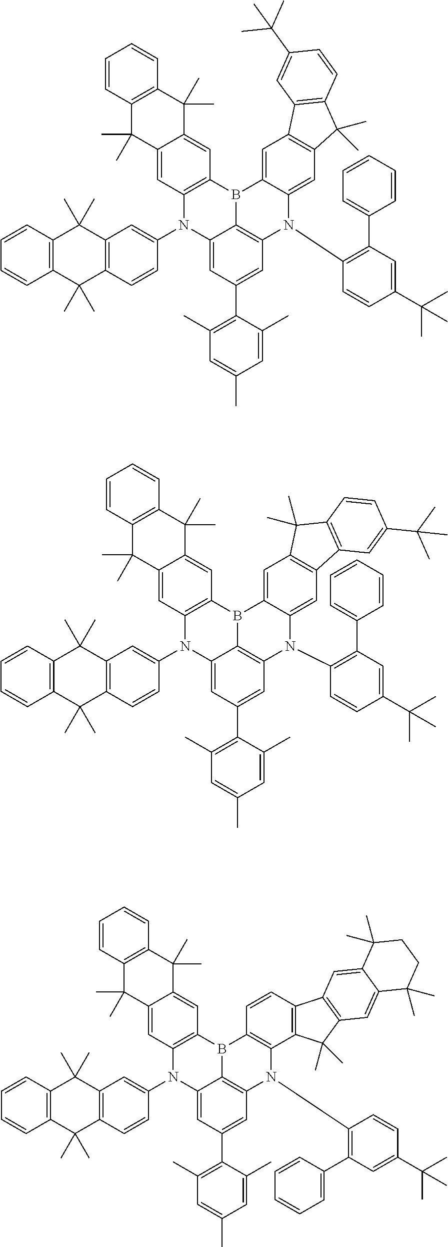

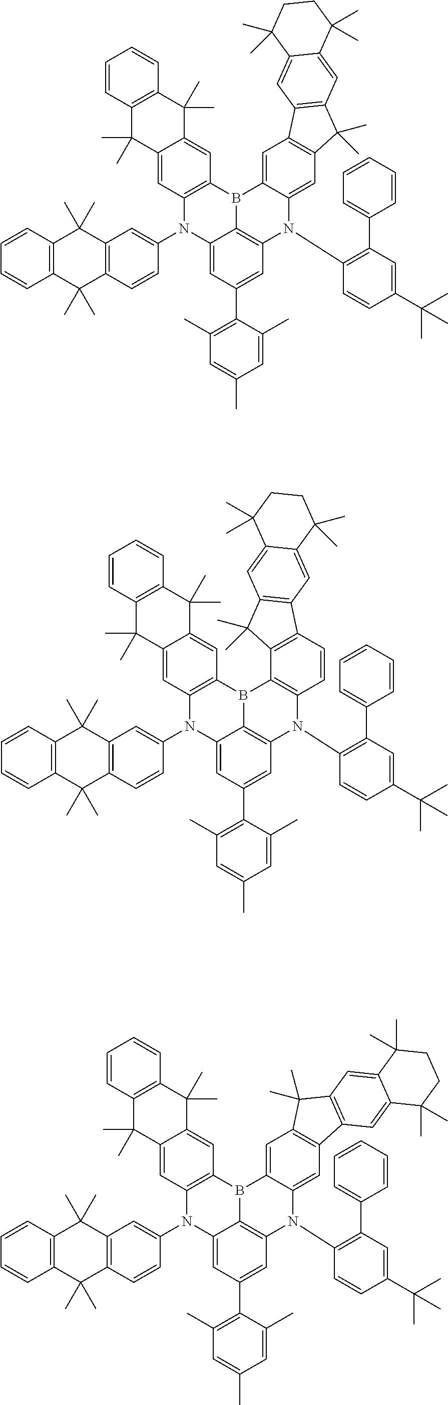

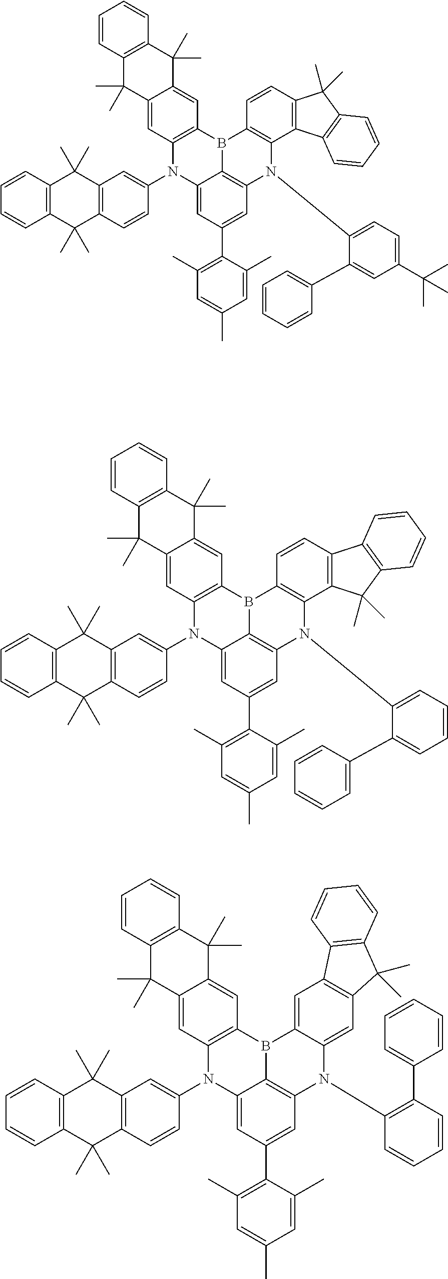 [SMILES: Cc1cc(C)c(-c2cc3c4c(c2)N(c2ccc(C(C)(C)C)cc2-c2ccccc2)c2c(ccc5c2-c2ccccc2C5(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2C(C)(C)c2ccccc2-5)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)-c2ccccc2C5(C)C)c(C)c1]

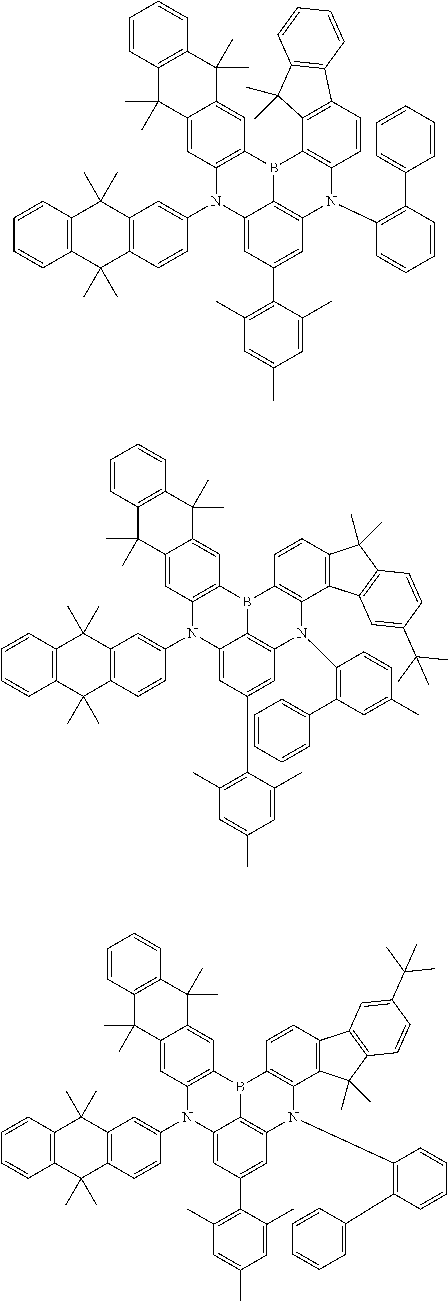 [SMILES: Cc1cc(C)c(-c2cc3c4c(c2)N(c2ccccc2-c2ccccc2)c2ccc5c(c2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1 ; Cc1cc(C)c(-c2cc3c4c(c2)N(c2ccc(C)cc2-c2ccccc2)c2c(ccc5c2-c2cc(C(C)(C)C)ccc2C5(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2c(ccc5c2C(C)(C)c2ccc(C(C)(C)C)cc2-5)B4c2cc4c(cc2N3c2ccc3c(c2)C(C)(C)c2ccccc2C3(C)C)C(C)(C)c2ccccc2C4(C)C)c(C)c1]

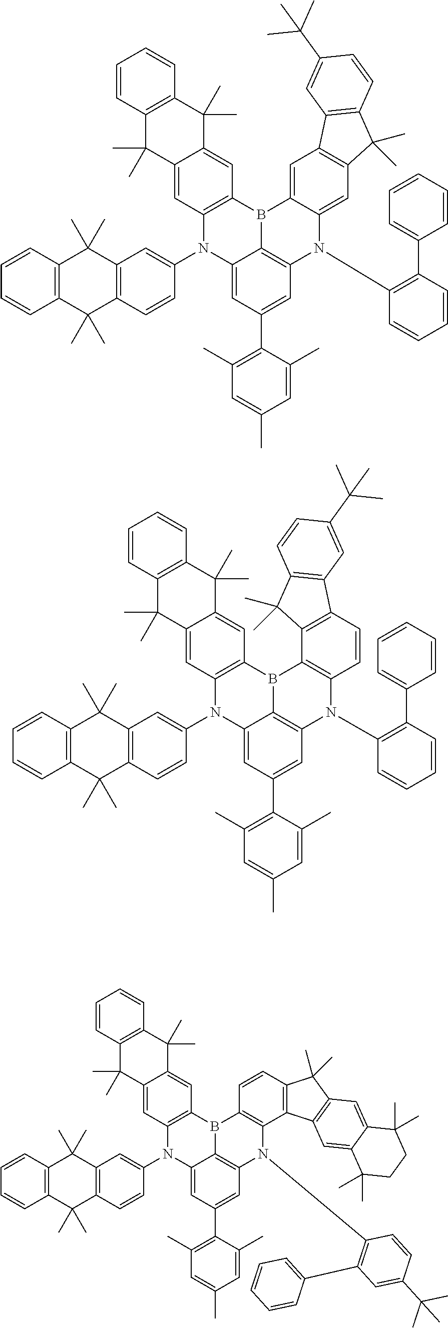 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)-c2cc(C(C)(C)C)ccc2C5(C)C)c(C)c1 ; Cc1cc(C)c(-c2cc3c4c(c2)N(c2ccccc2-c2ccccc2)c2ccc5c(c2B4c2cc4c(cc2N3c2ccc3c(c2)C(C)(C)c2ccccc2C3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccc(C(C)(C)C)cc2-c2ccccc2)c2c(ccc5c2-c2cc6c(cc2C5(C)C)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

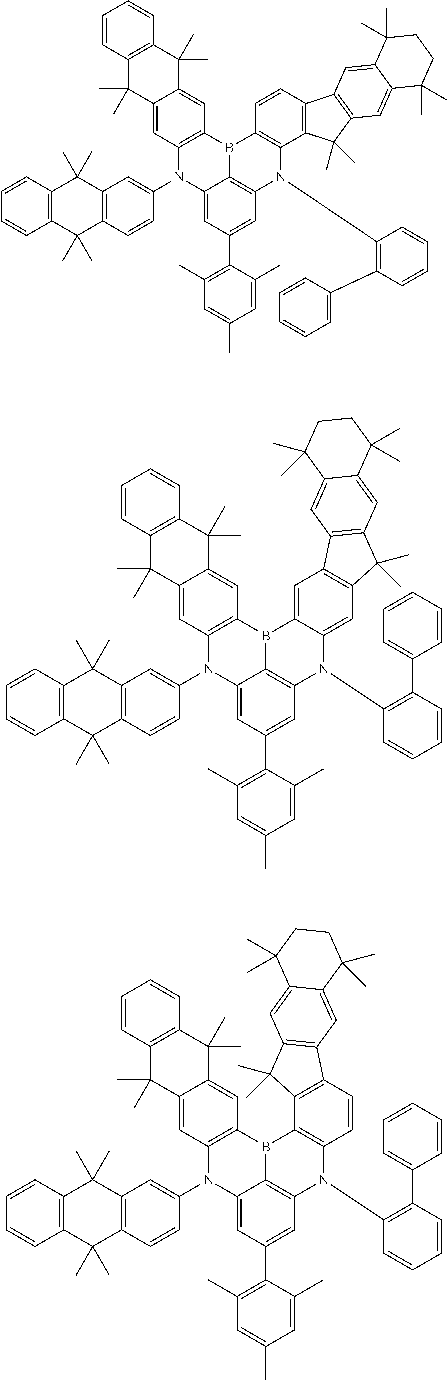 [SMILES: Cc1cc(C)c(-c2cc3c4c(c2)N(c2ccccc2-c2ccccc2)c2c(ccc5c2C(C)(C)c2cc6c(cc2-5)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)-c2cc3c(cc2C5(C)C)C(C)(C)CCC3(C)C)c(C)c1 ; Cc1cc(C)c(-c2cc3c4c(c2)N(c2ccccc2-c2ccccc2)c2ccc5c(c2B4c2cc4c(cc2N3c2ccc3c(c2)C(C)(C)c2ccccc2C3(C)C)C(C)(C)c2ccccc2C4(C)C)C(C)(C)c2cc3c(cc2-5)C(C)(C)CCC3(C)C)c(C)c1]

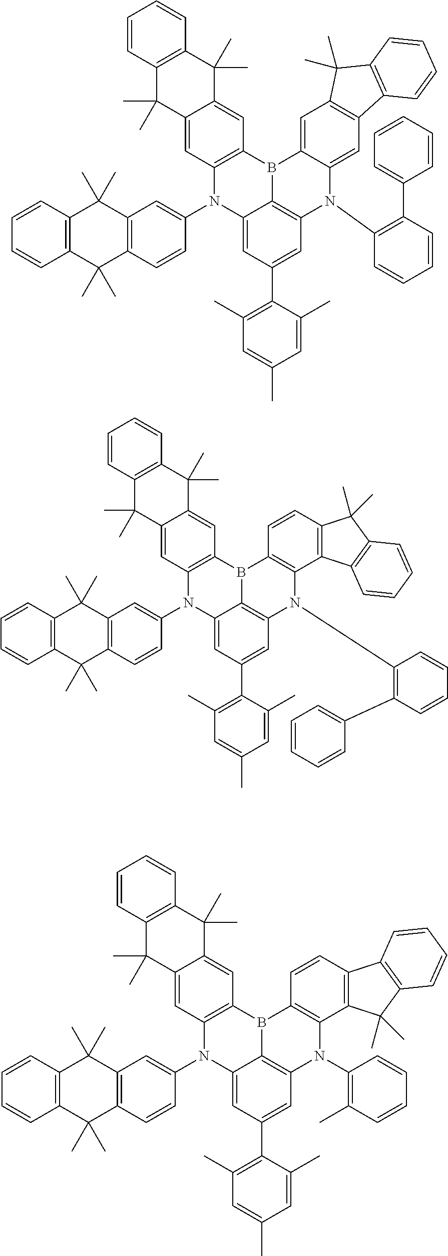 [SMILES: Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1 ; Cc1cc(C)c(-c2cc3c4c(c2)N(c2ccccc2-c2ccccc2)c2c(ccc5c2-c2ccccc2C5(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2C(C)(C)c2ccccc2-5)B4c2cc4c(cc2N3c2ccc3c(c2)C(C)(C)c2ccccc2C3(C)C)C(C)(C)c2ccccc2C4(C)C)c(C)c1]

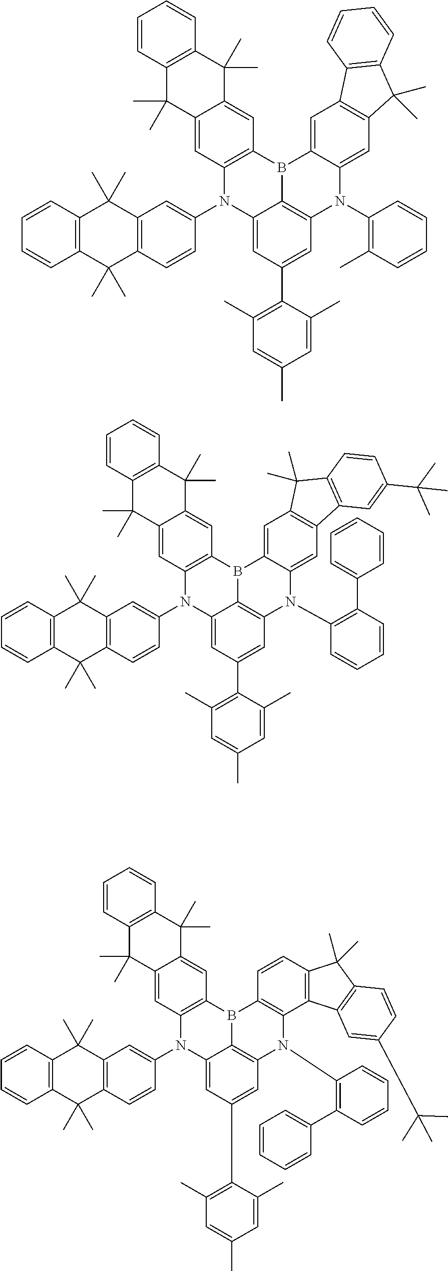 [SMILES: Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)-c2ccccc2C5(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccccc2-c2ccccc2)c2c(ccc5c2-c2cc(C(C)(C)C)ccc2C5(C)C)B4c2cc4c(cc2N3c2ccc3c(c2)C(C)(C)c2ccccc2C3(C)C)C(C)(C)c2ccccc2C4(C)C)c(C)c1]

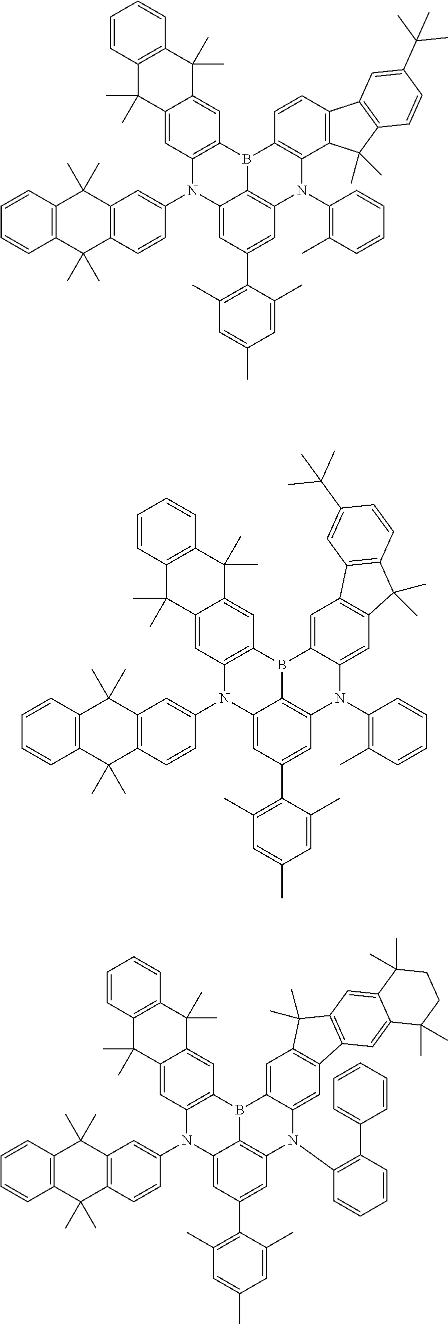 [SMILES: Cc1cc(C)c(-c2cc3c4c(c2)N(c2ccccc2C)c2c(ccc5c2C(C)(C)c2ccc(C(C)(C)C)cc2-5)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)-c2cc(C(C)(C)C)ccc2C5(C)C)c(C)c1 ; Cc1cc(C)c(-c2cc3c4c(c2)N(c2ccccc2-c2ccccc2)c2cc5c(cc2B4c2cc4c(cc2N3c2ccc3c(c2)C(C)(C)c2ccccc2C3(C)C)C(C)(C)c2ccccc2C4(C)C)C(C)(C)c2cc3c(cc2-5)C(C)(C)CCC3(C)C)c(C)c1]

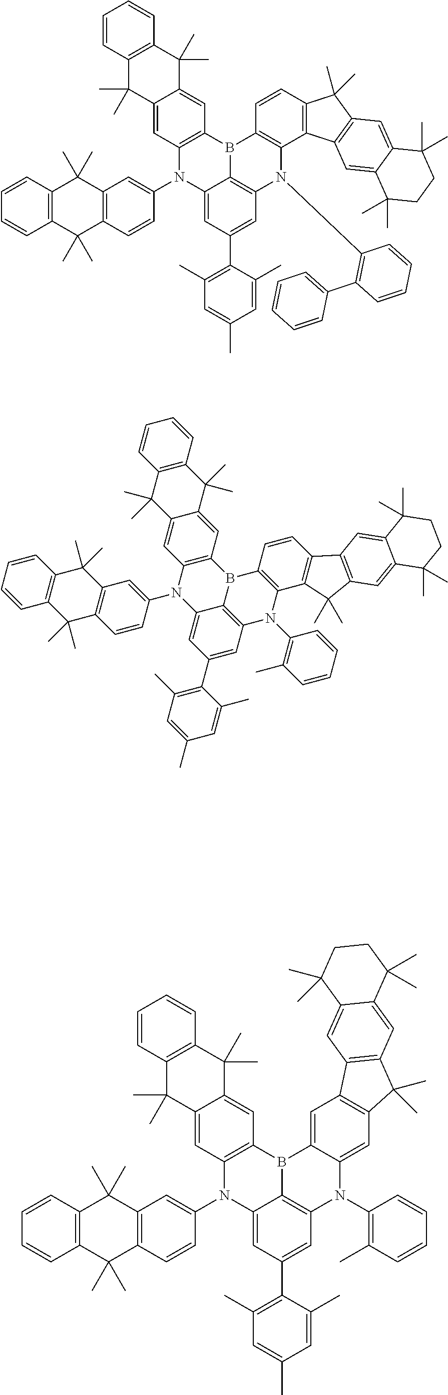 [SMILES: Cc1cc(C)c(-c2cc3c4c(c2)N(c2ccccc2-c2ccccc2)c2c(ccc5c2-c2cc6c(cc2C5(C)C)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2c(ccc5c2C(C)(C)c2cc6c(cc2-5)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)-c2cc3c(cc2C5(C)C)C(C)(C)CCC3(C)C)c(C)c1]

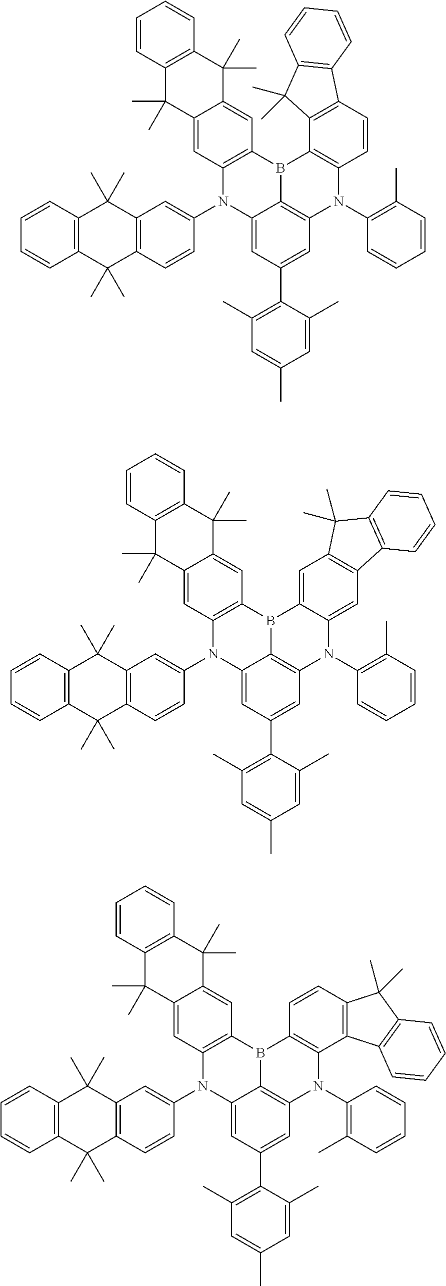 [SMILES: Cc1cc(C)c(-c2cc3c4c(c2)N(c2ccccc2C)c2ccc5c(c2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1 ; Cc1cc(C)c(-c2cc3c4c(c2)N(c2ccccc2C)c2c(ccc5c2-c2ccccc2C5(C)C)B4c2cc4c(cc2N3c2ccc3c(c2)C(C)(C)c2ccccc2C3(C)C)C(C)(C)c2ccccc2C4(C)C)c(C)c1]

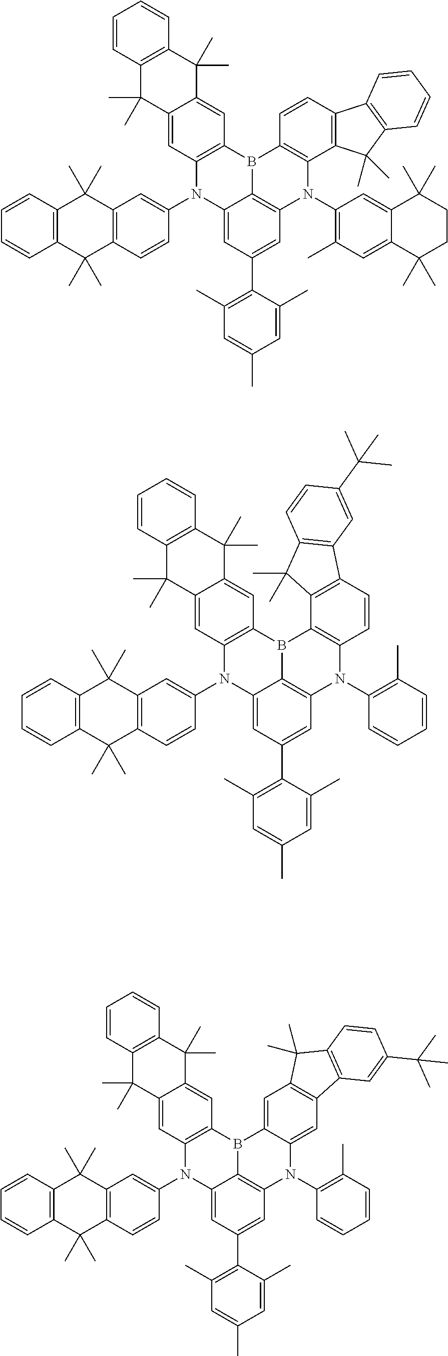 [SMILES: Cc1cc(C)c(-c2cc3c4c(c2)N(c2cc5c(cc2C)C(C)(C)CCC5(C)C)c2c(ccc5c2C(C)(C)c2ccccc2-5)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(c2B4c2cc4c(cc2N3c2ccc3c(c2)C(C)(C)c2ccccc2C3(C)C)C(C)(C)c2ccccc2C4(C)C)C(C)(C)c2ccc(C(C)(C)C)cc2-5)c(C)c1 ; Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)C(C)(C)c2ccc(C(C)(C)C)cc2-5)c(C)c1]

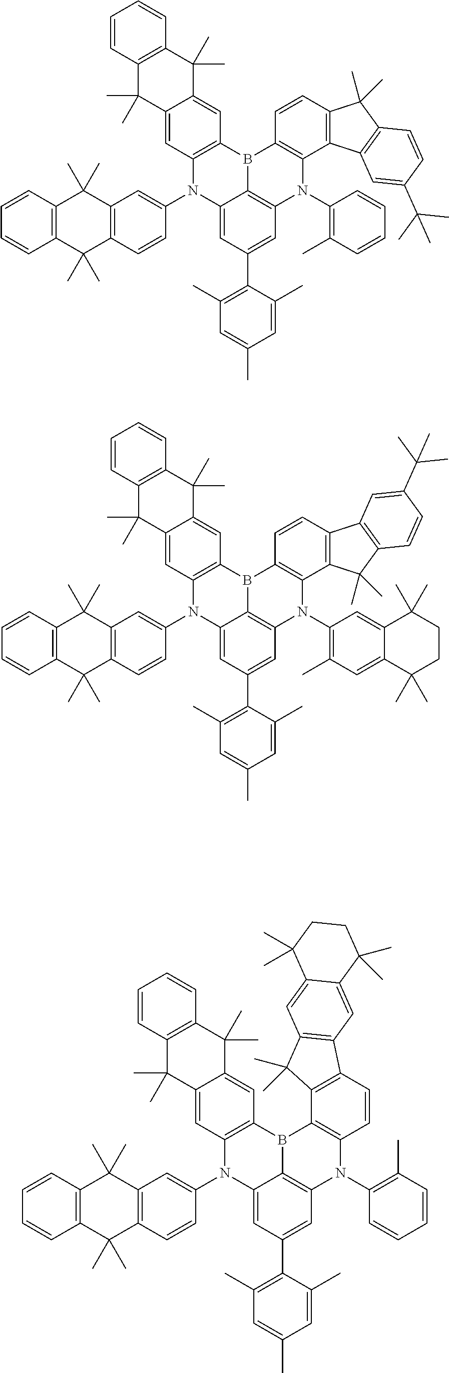 [SMILES: Cc1cc(C)c(-c2cc3c4c(c2)N(c2ccccc2C)c2c(ccc5c2-c2cc(C(C)(C)C)ccc2C5(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2C(C)(C)c2ccc(C(C)(C)C)cc2-5)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2ccccc2C)c2ccc5c(c2B4c2cc4c(cc2N3c2ccc3c(c2)C(C)(C)c2ccccc2C3(C)C)C(C)(C)c2ccccc2C4(C)C)C(C)(C)c2cc3c(cc2-5)C(C)(C)CCC3(C)C)c(C)c1]

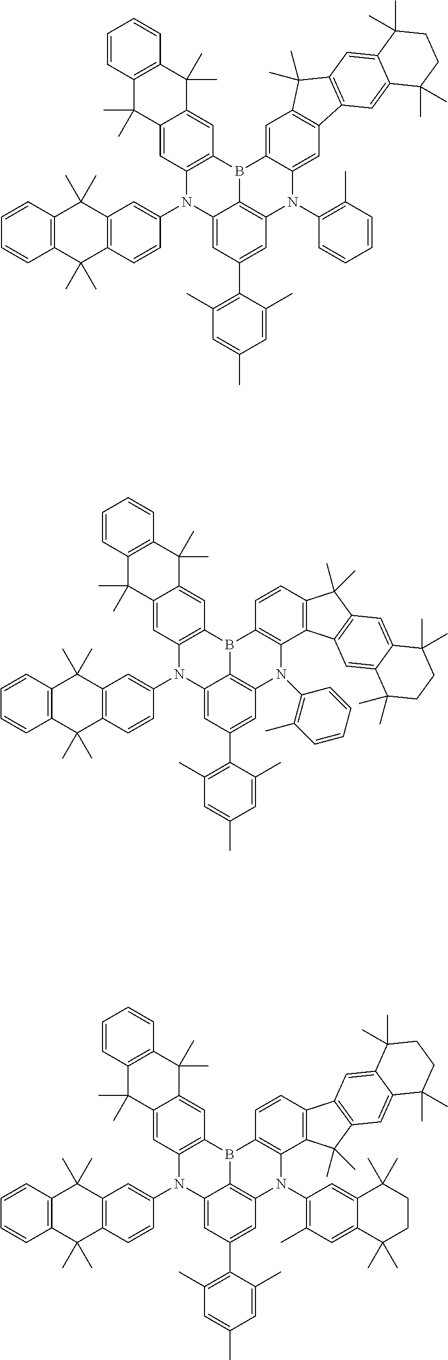 [SMILES: Cc1cc(C)c(-c2cc3c4c(c2)N(c2ccccc2C)c2cc5c(cc2B4c2cc4c(cc2N3c2ccc3c(c2)C(C)(C)c2ccccc2C3(C)C)C(C)(C)c2ccccc2C4(C)C)C(C)(C)c2cc3c(cc2-5)C(C)(C)CCC3(C)C)c(C)c1 ; Cc1cc(C)c(-c2cc3c4c(c2)N(c2ccccc2C)c2c(ccc5c2-c2cc6c(cc2C5(C)C)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1 ; Cc1cc(C)c(-c2cc3c4c(c2)N(c2cc5c(cc2C)C(C)(C)CCC5(C)C)c2c(ccc5c2C(C)(C)c2cc6c(cc2-5)C(C)(C)CCC6(C)C)B4c2cc4c(cc2N3c2ccc3c(c2)C(C)(C)c2ccccc2C3(C)C)C(C)(C)c2ccccc2C4(C)C)c(C)c1]

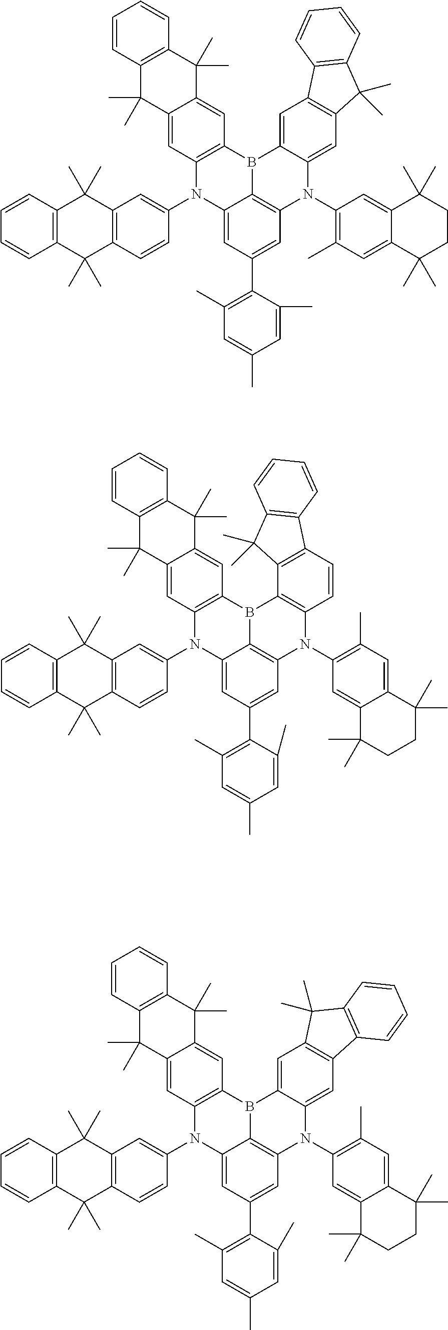 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)-c2ccccc2C5(C)C)c(C)c1 ; Cc1cc(C)c(-c2cc3c4c(c2)N(c2cc5c(cc2C)C(C)(C)CCC5(C)C)c2ccc5c(c2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)c2ccccc2C3(C)C)C(C)(C)c2ccccc2C4(C)C)C(C)(C)c2ccccc2-5)c(C)c1]

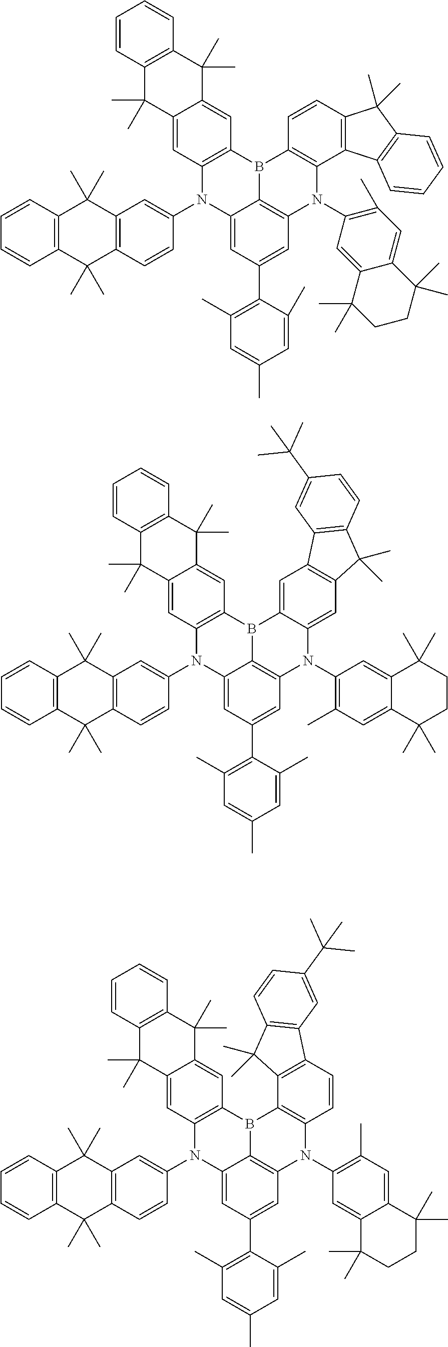

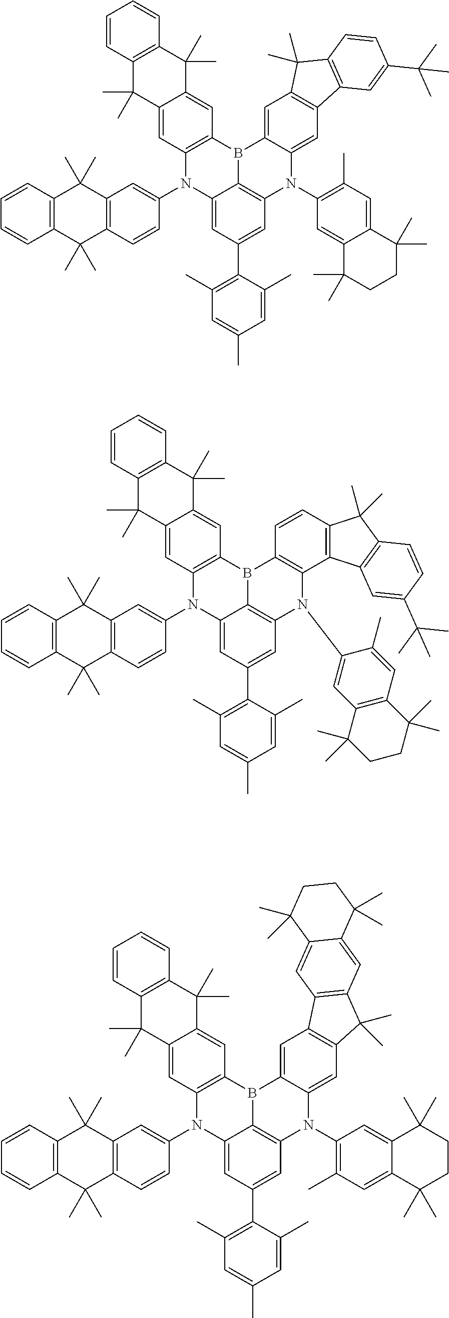

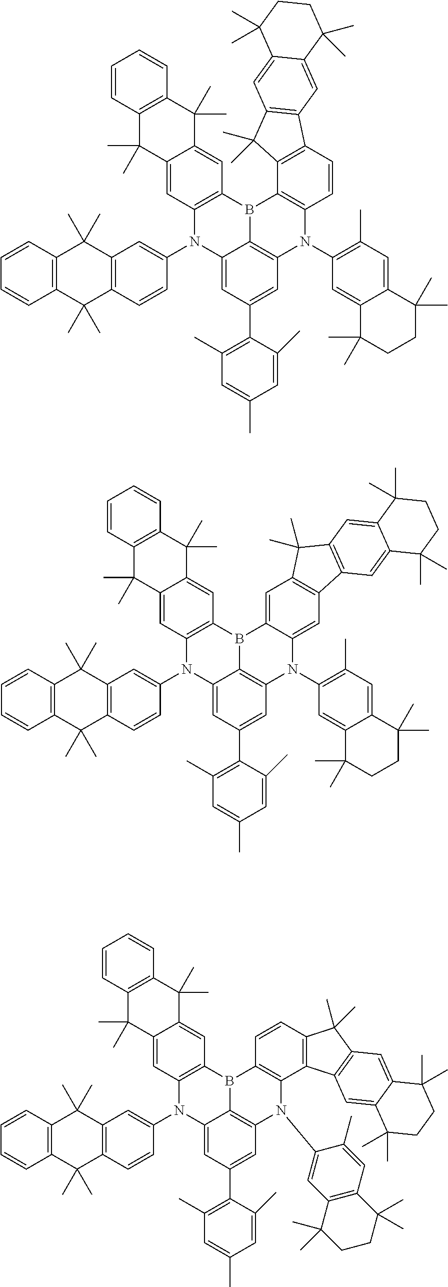

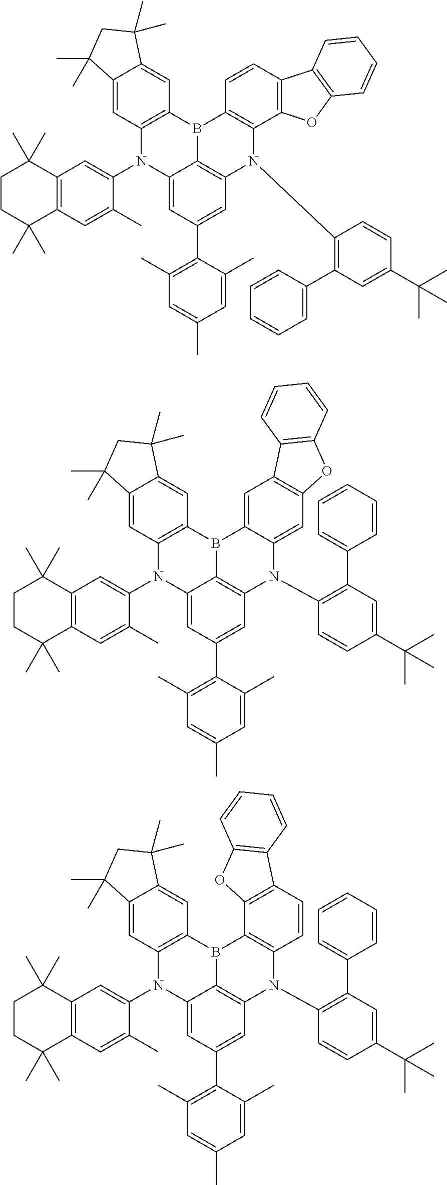

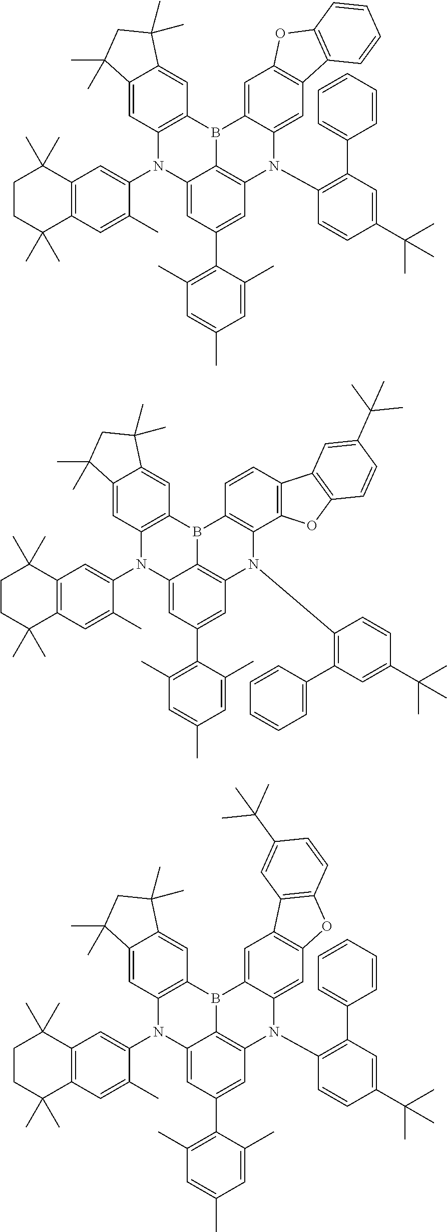 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)oc2ccccc25)c(C)c1 ; Cc1cc(C)c(-c2cc3c4c(c2)N(c2ccc(C(C)(C)C)cc2-c2ccccc2)c2c(ccc5c2oc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc4c(cc2N3c2cc3c(cc2C)C(C)(C)CCC3(C)C)C(C)(C)CC4(C)C)c(C)c1]

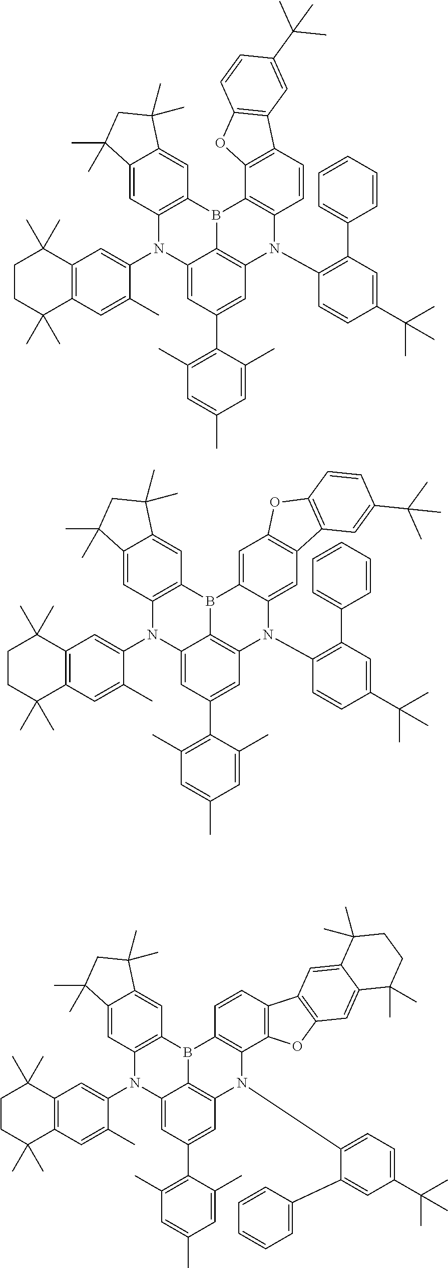 [SMILES: Cc1cc(C)c(-c2cc3c4c(c2)N(c2ccc(C(C)(C)C)cc2-c2ccccc2)c2ccc5c(oc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

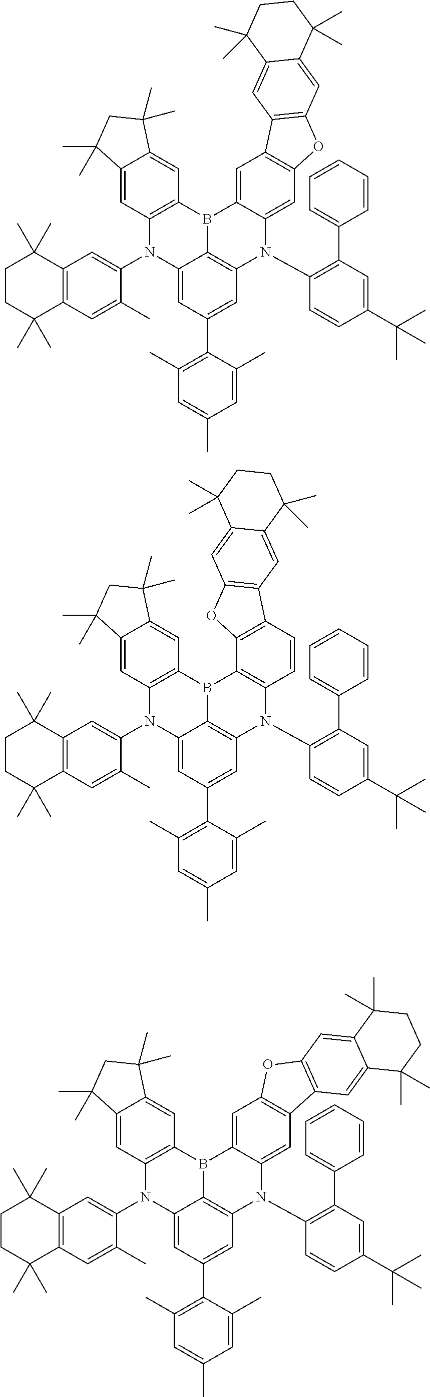

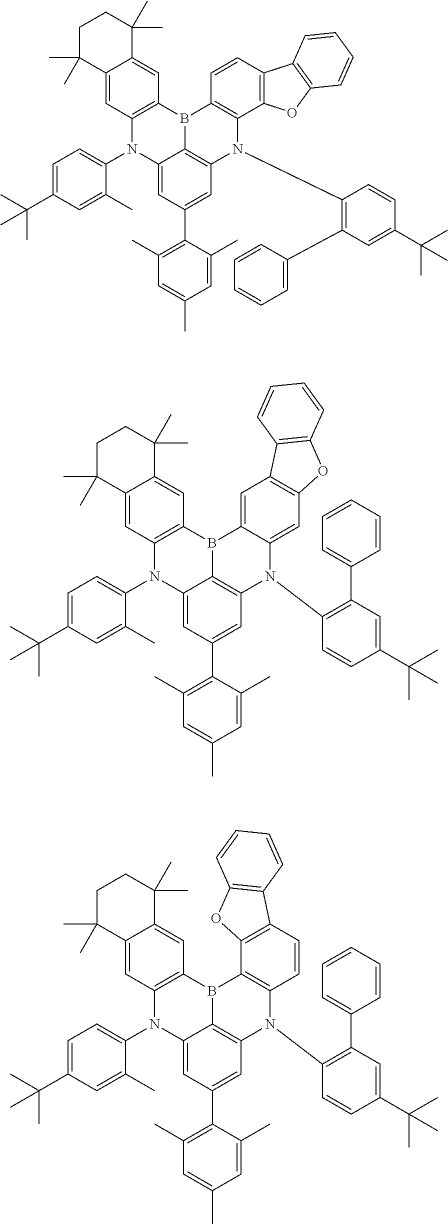

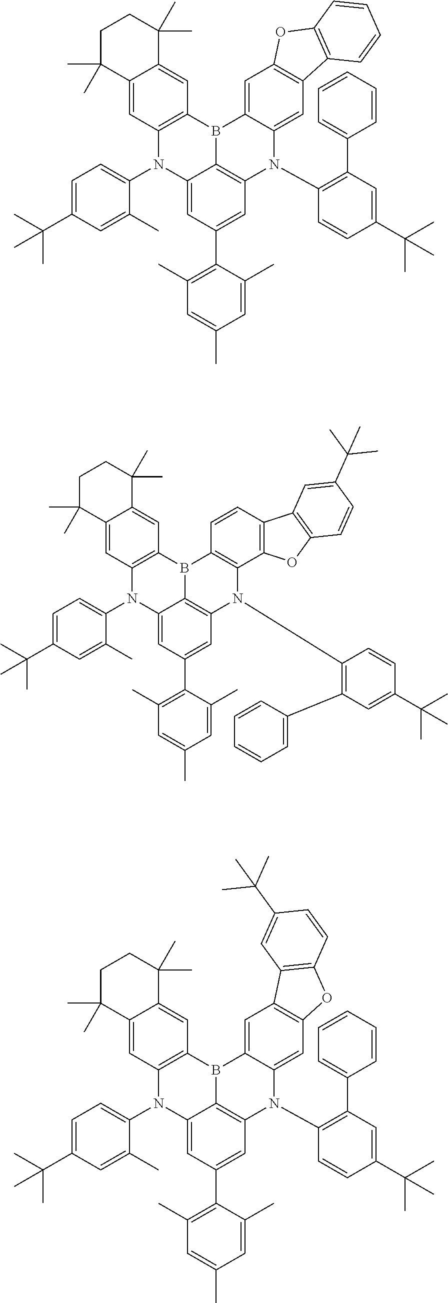

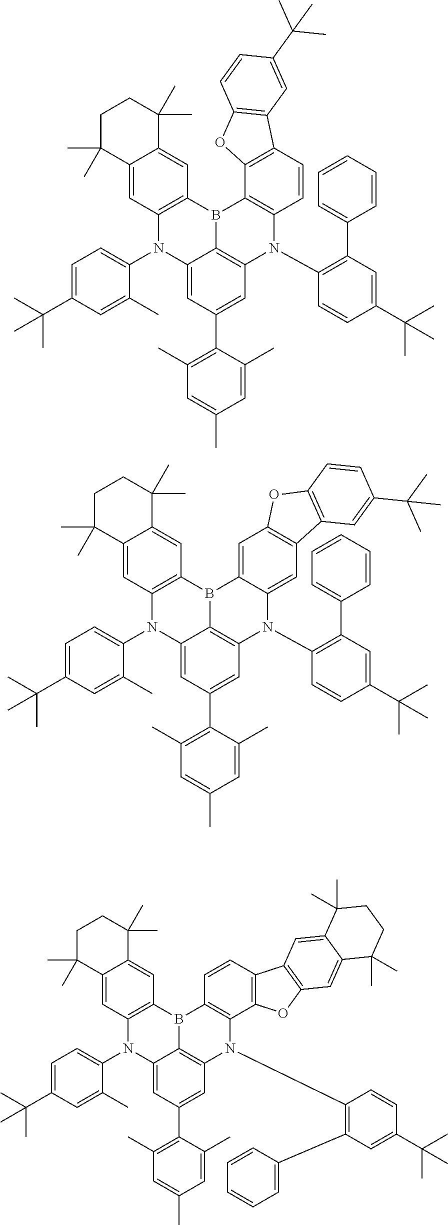

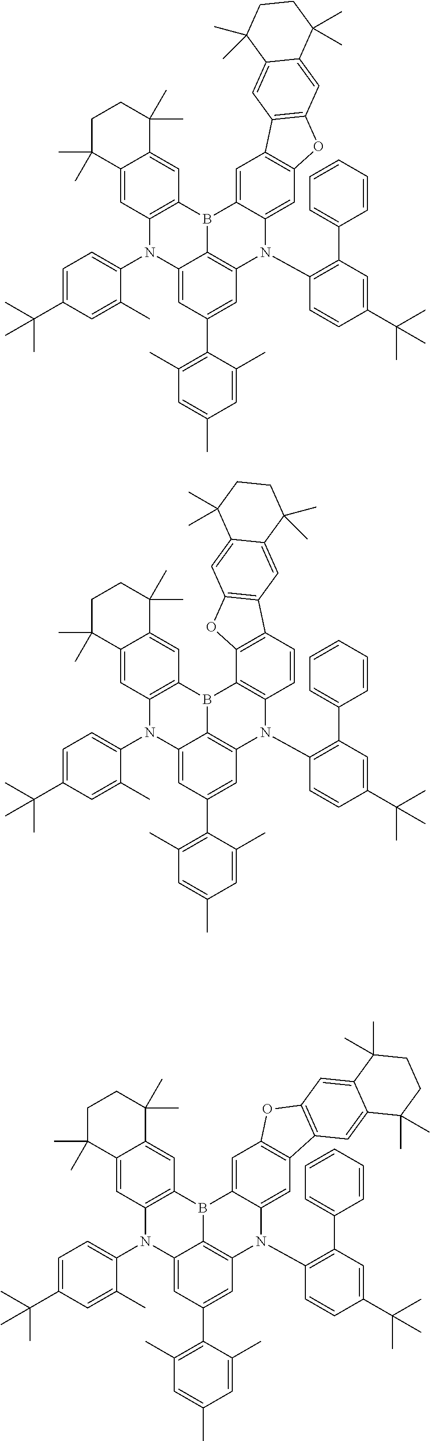

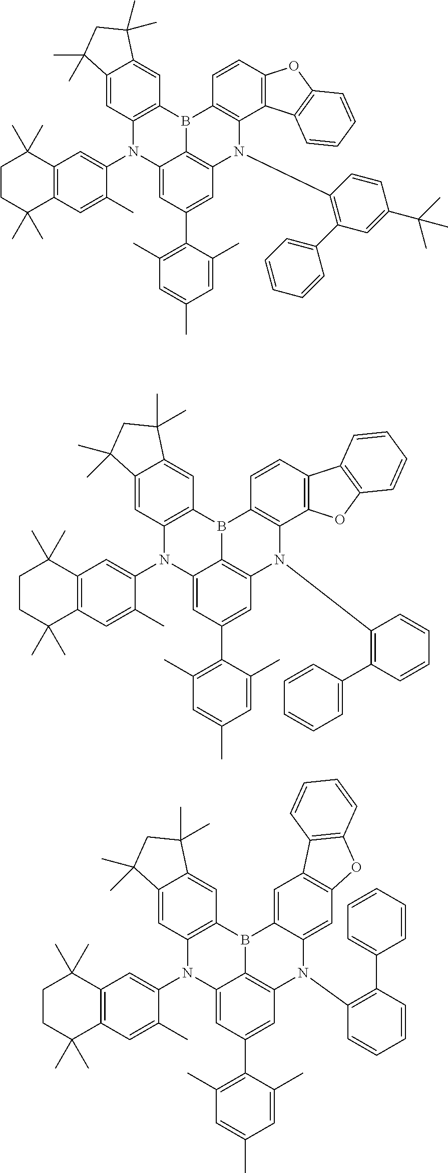 [SMILES: Cc1cc(C)c(-c2cc3c4c(c2)N(c2ccc(C(C)(C)C)cc2-c2ccccc2)c2c(ccc5oc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2c(ccc5c2oc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5oc6ccccc6c5cc2B4c2cc4c(cc2N3c2cc3c(cc2C)C(C)(C)CCC3(C)C)C(C)(C)CC4(C)C)c(C)c1]

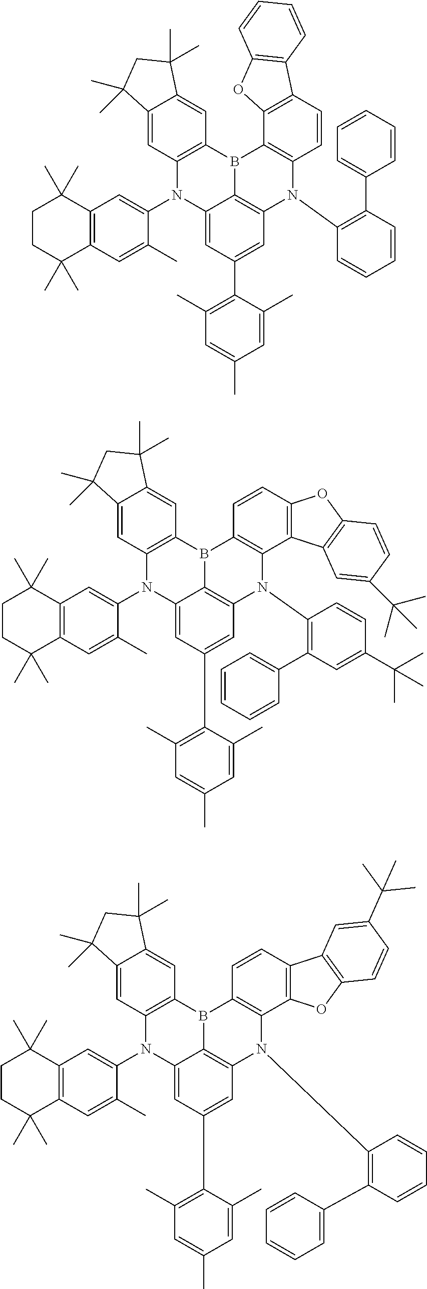 [SMILES: Cc1cc(C)c(-c2cc3c4c(c2)N(c2ccccc2-c2ccccc2)c2ccc5c(oc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2c(ccc5oc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc4c(cc2N3c2cc3c(cc2C)C(C)(C)CCC3(C)C)C(C)(C)CC4(C)C)c(C)c1]

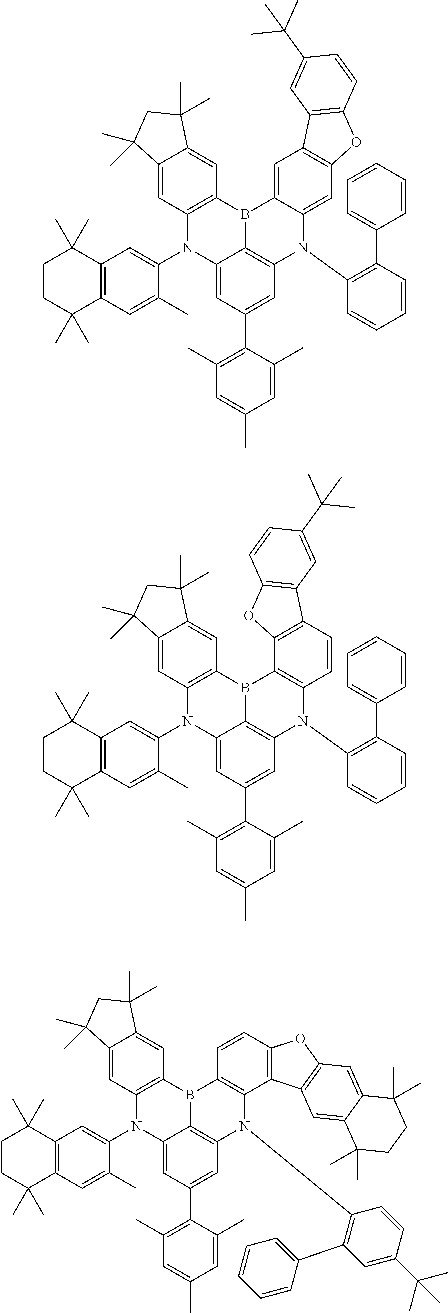 [SMILES: Cc1cc(C)c(-c2cc3c4c(c2)N(c2ccccc2-c2ccccc2)c2cc5oc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2ccc5c(oc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1]

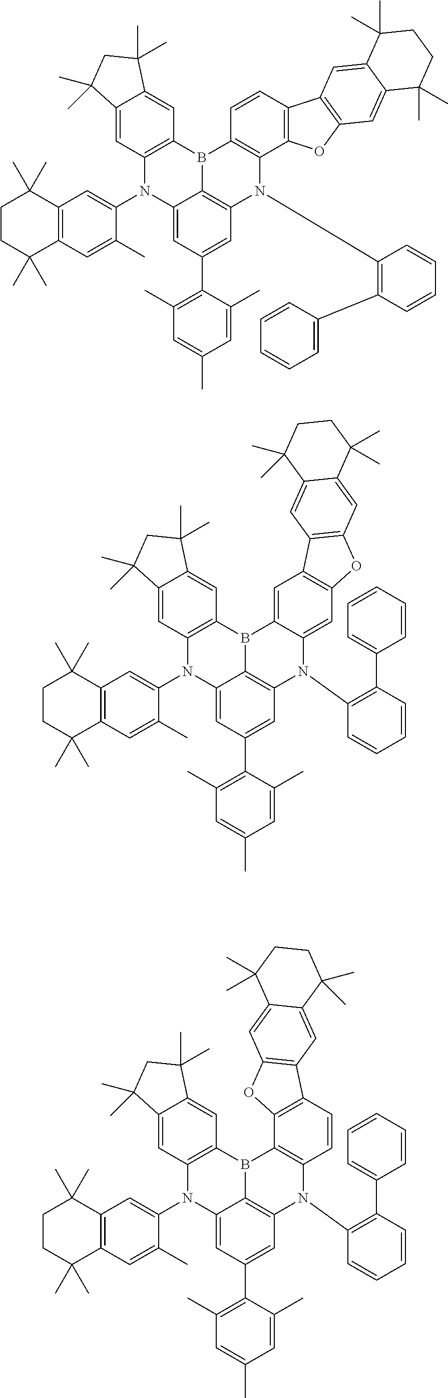 [SMILES: Cc1cc(C)c(-c2cc3c4c(c2)N(c2ccccc2-c2ccccc2)c2c(ccc5c2oc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5oc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1 ; Cc1cc(C)c(-c2cc3c4c(c2)N(c2ccccc2-c2ccccc2)c2ccc5c(oc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

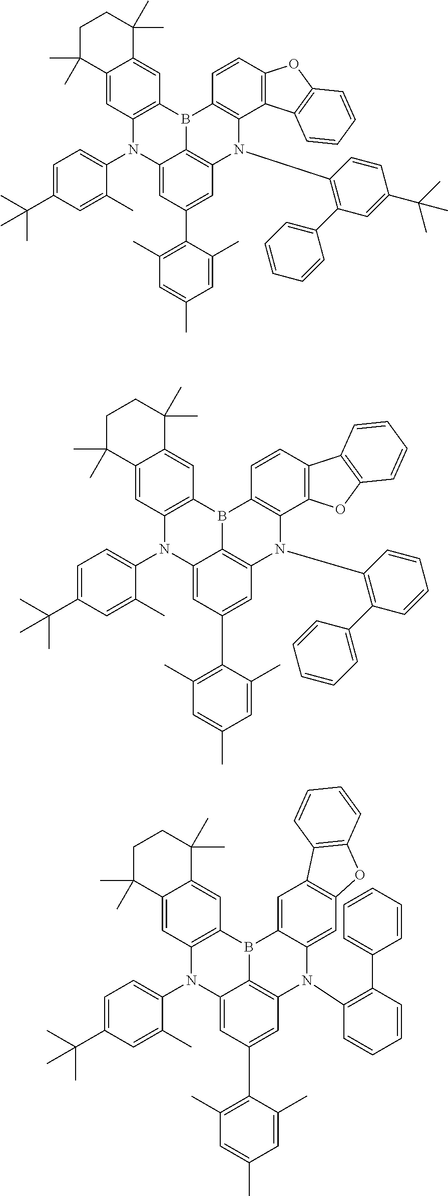

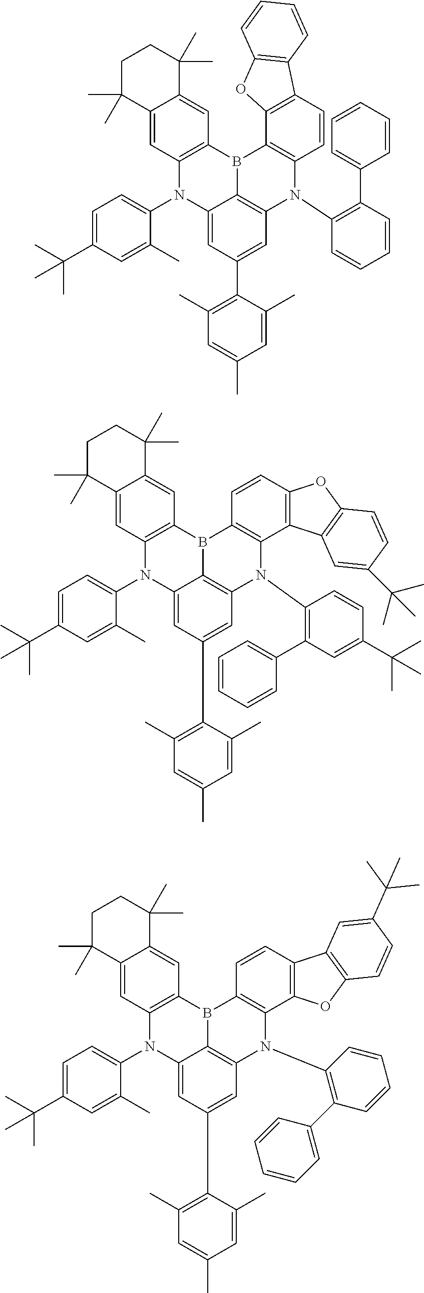

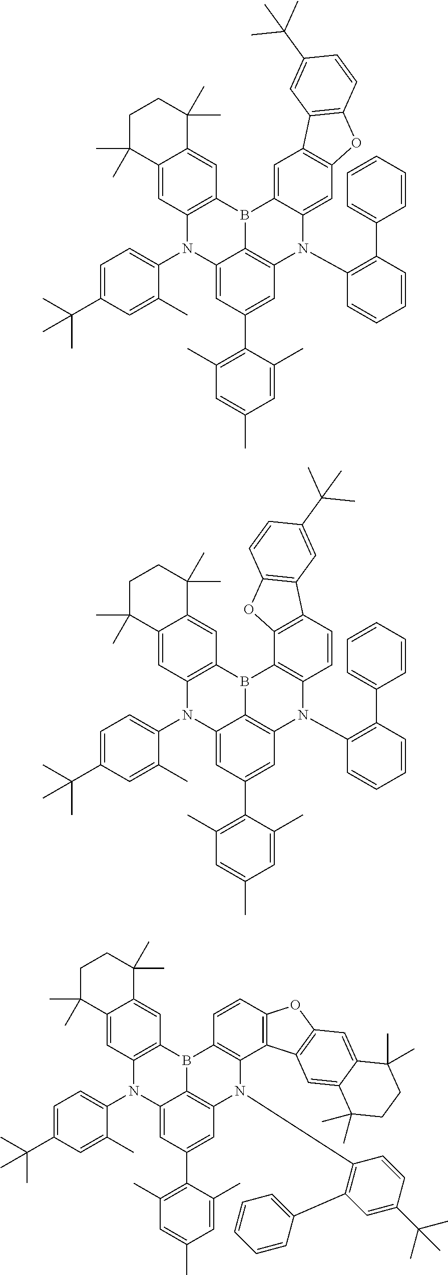 [SMILES: Cc1cc(C)c(-c2cc3c4c(c2)N(c2ccccc2-c2ccccc2)c2cc5oc6ccc(C(C)(C)C)cc6c5cc2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2-c2ccccc2)c2ccc5c(oc6ccc(C(C)(C)C)cc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2ccc(C(C)(C)C)cc2C)C(C)(C)CCC4(C)C)c(C)c1]

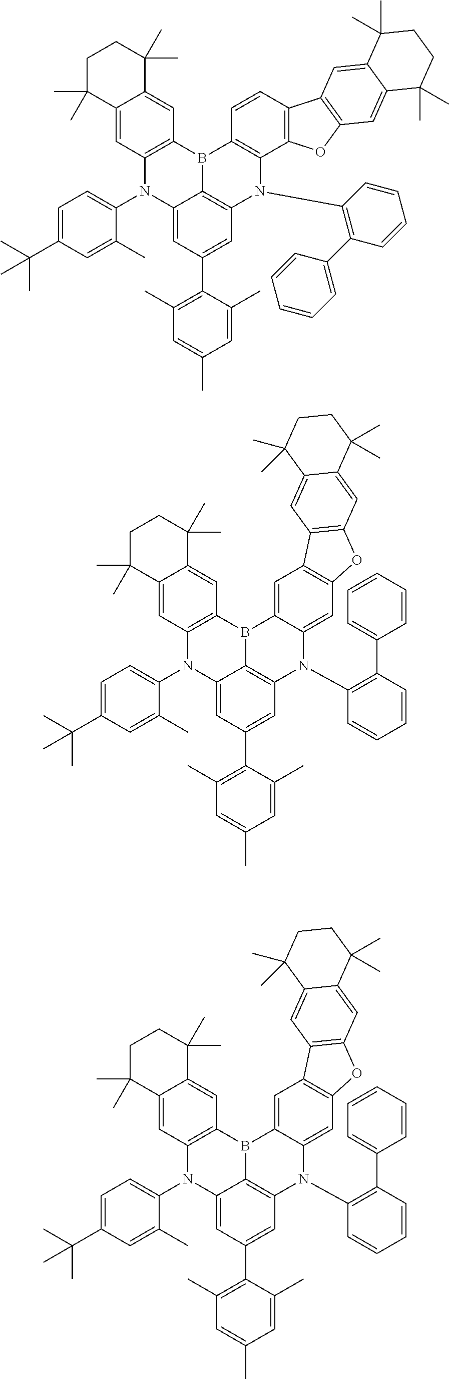

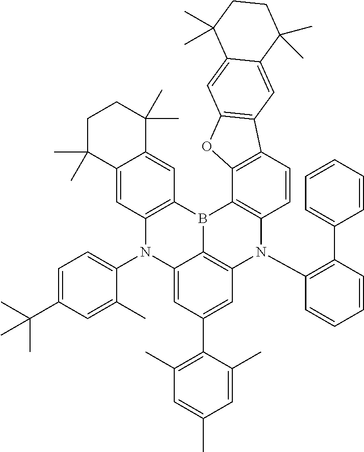 [SMILES: Cc1cc(C)c(-c2cc3c4c(c2)N(c2ccccc2-c2ccccc2)c2ccc5c(oc6cc7c(cc65)C(C)(C)CCC7(C)C)c2B4c2cc4c(cc2N3c2ccc(C(C)(C)C)cc2C)C(C)(C)CCC4(C)C)c(C)c1]

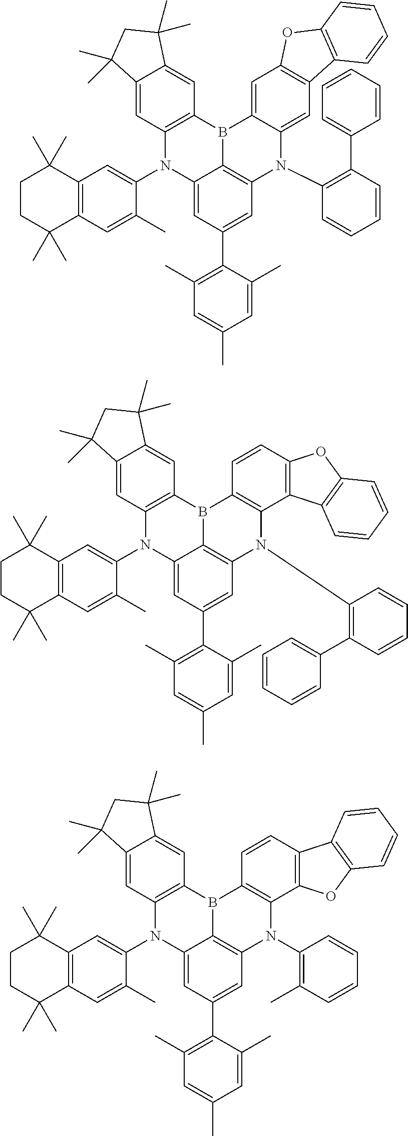 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2oc2ccccc25)B4c2cc4c(cc2N3c2cc3c(cc2C)C(C)(C)CCC3(C)C)C(C)(C)CC4(C)C)c(C)c1]

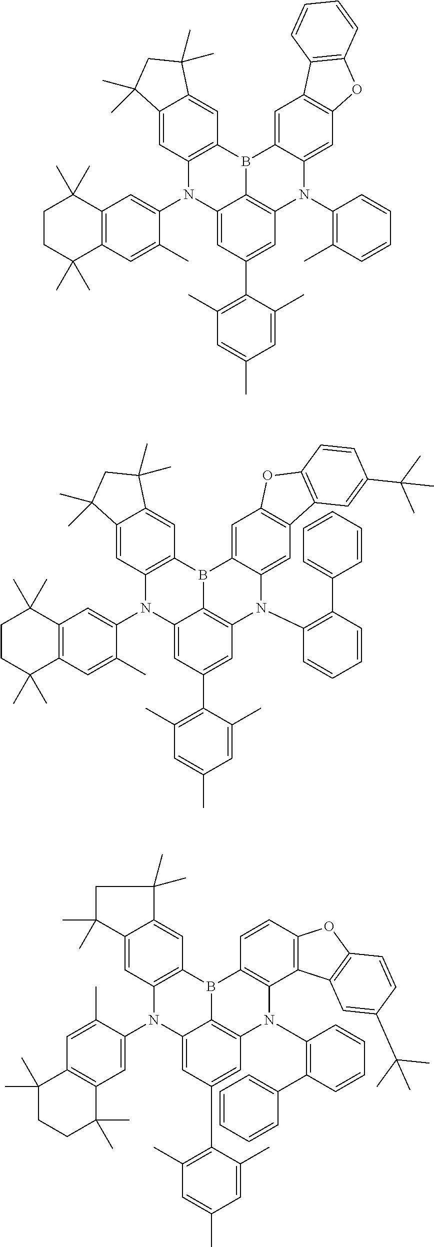

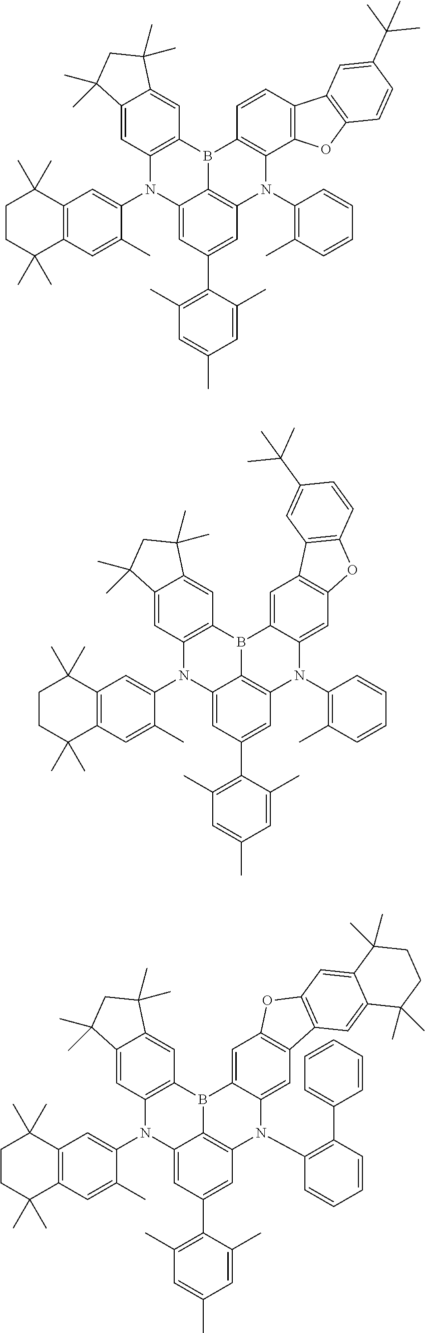 [SMILES: Cc1cc(C)c(-c2cc3c4c(c2)N(c2ccccc2C)c2c(ccc5c2oc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5oc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)oc2cc3c(cc25)C(C)(C)CCC3(C)C)c(C)c1]

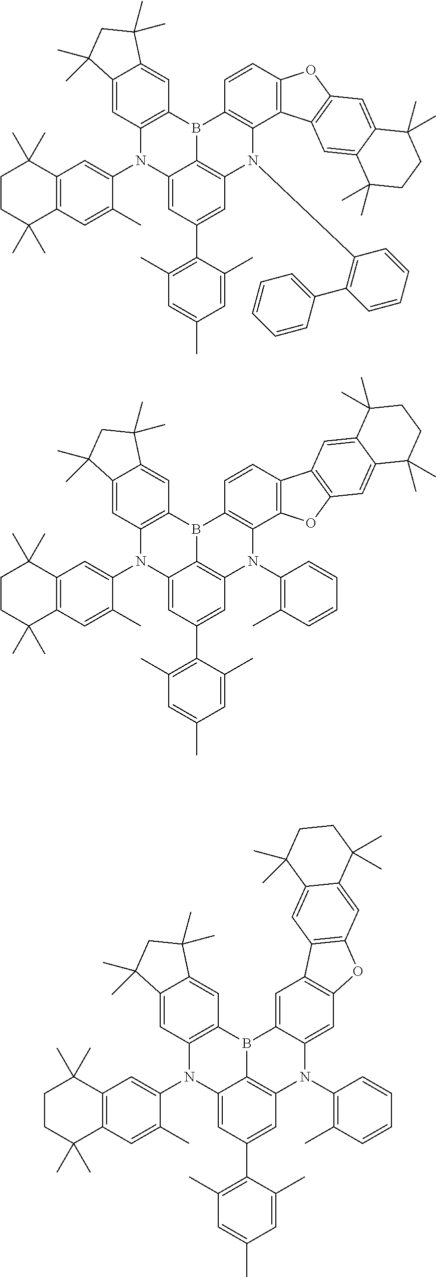 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5oc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

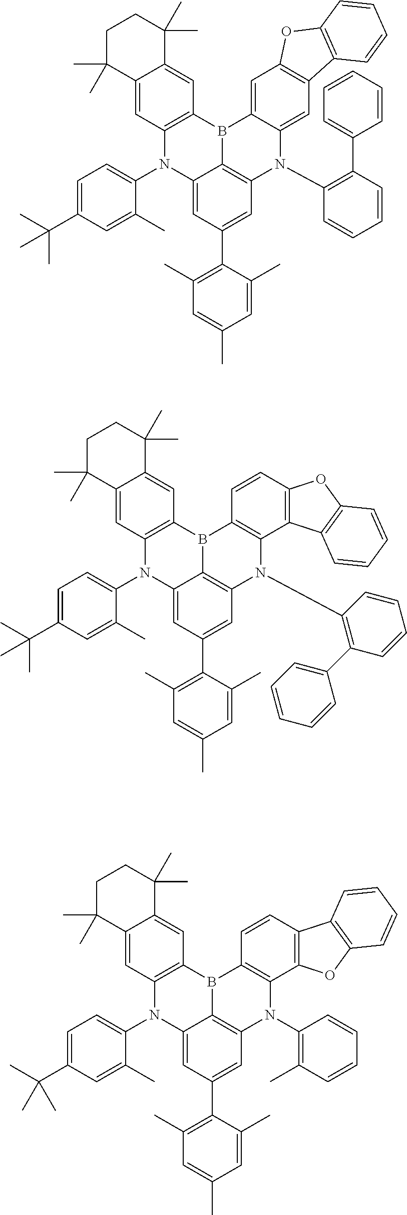 [SMILES: Cc1cc(C)c(-c2cc3c4c(c2)N(c2ccccc2-c2ccccc2)c2cc5c(cc2B4c2cc4c(cc2N3c2ccc(C(C)(C)C)cc2C)C(C)(C)CCC4(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2c(ccc5c2oc2ccccc25)B4c2cc4c(cc2N3c2ccc(C(C)(C)C)cc2C)C(C)(C)CCC4(C)C)c(C)c1]

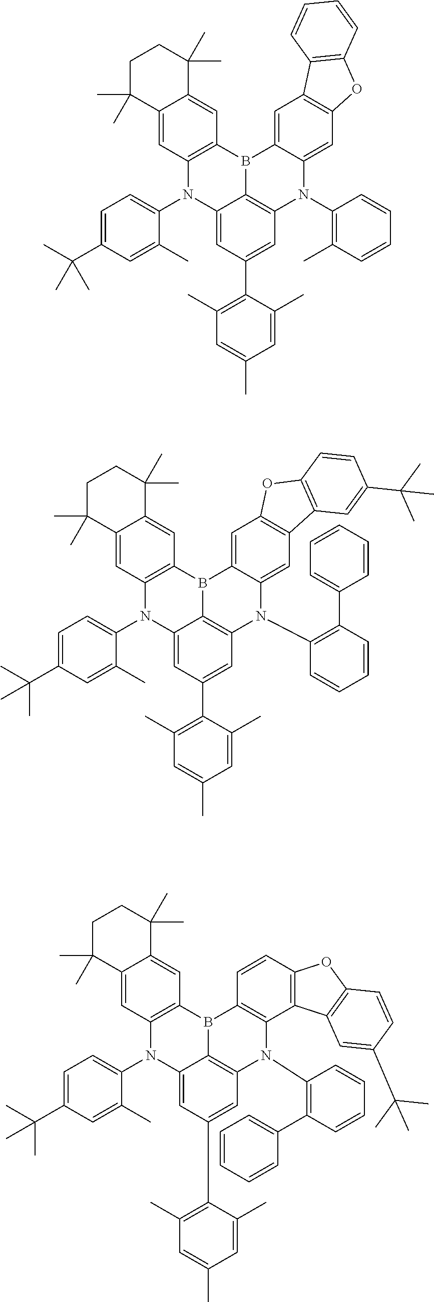

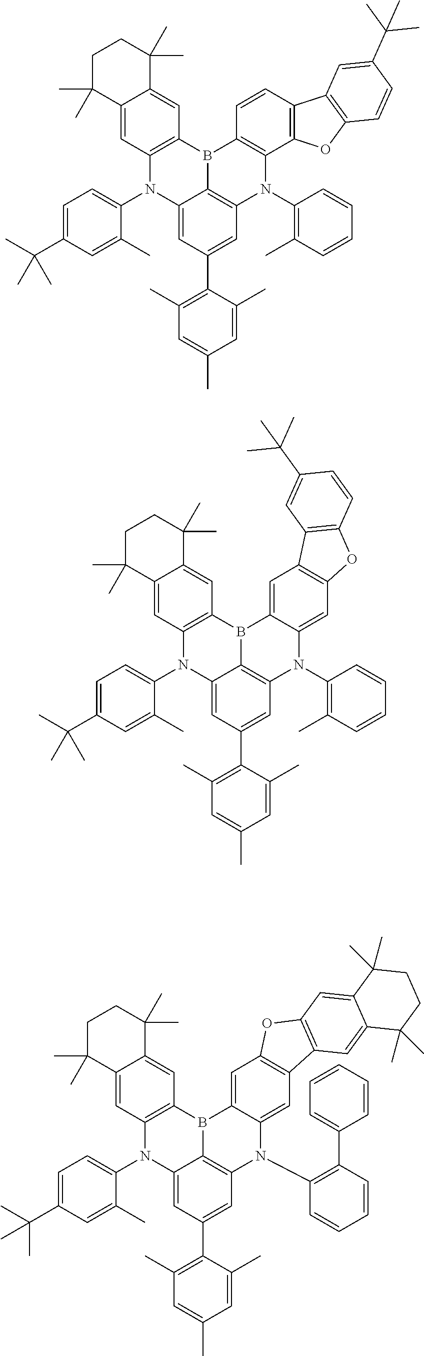

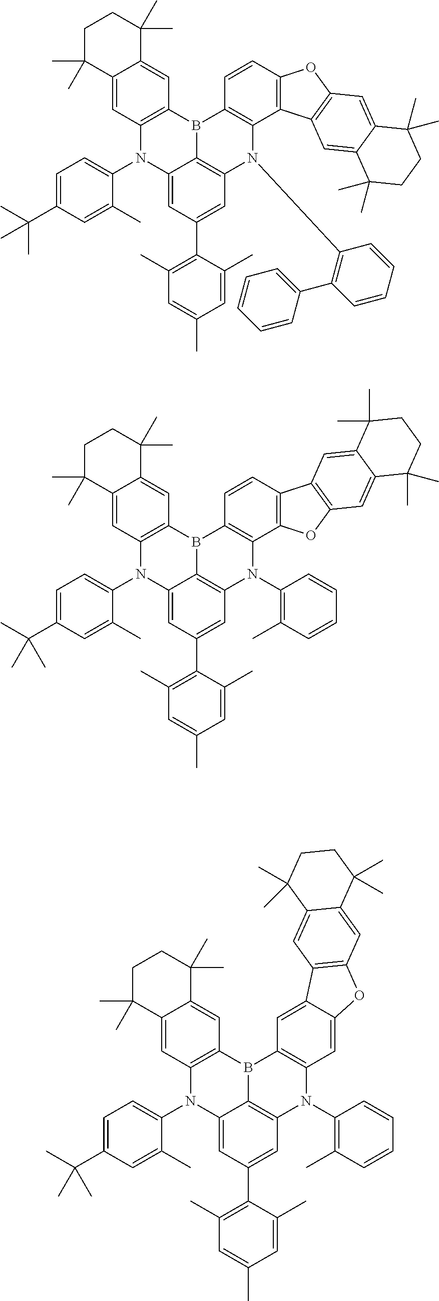

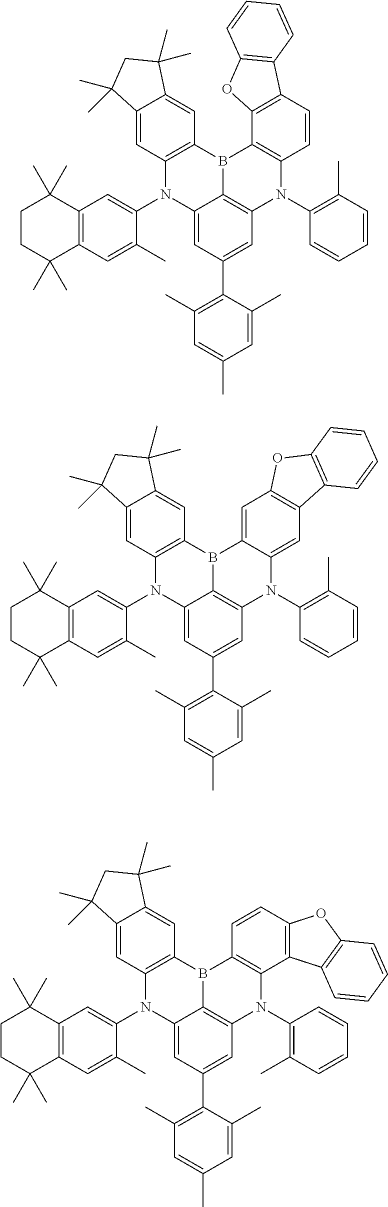 [SMILES: Cc1cc(C)c(-c2cc3c4c(c2)N(c2ccccc2C)c2ccc5c(oc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2cc3c(cc2C)C(C)(C)CCC3(C)C)C(C)(C)CC4(C)C)c(C)c1]

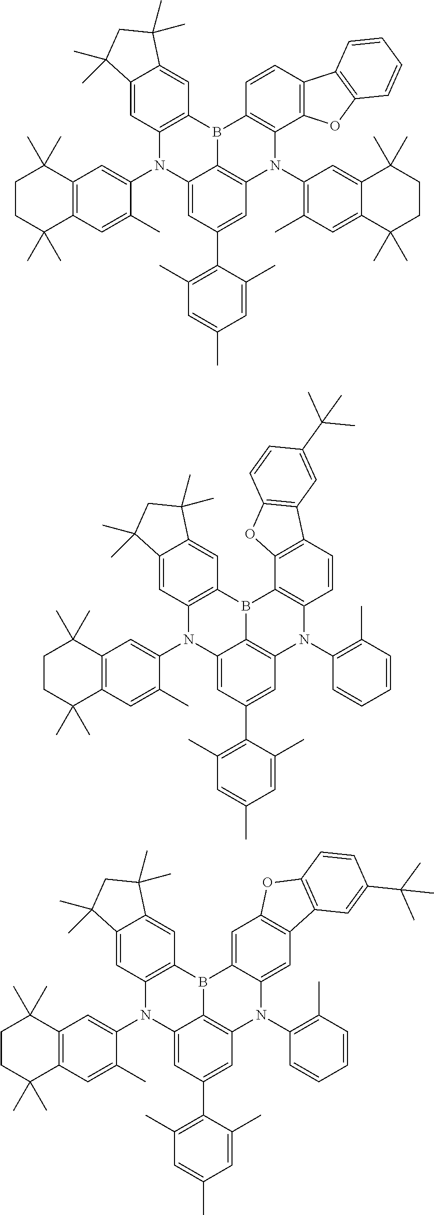 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)oc2ccc(C(C)(C)C)cc25)c(C)c1]

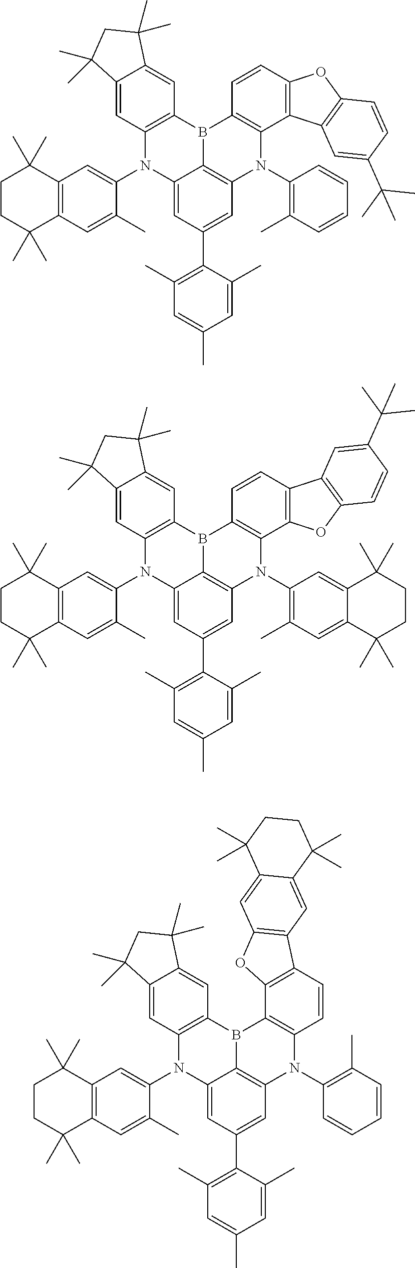 [SMILES: Cc1cc(C)c(-c2cc3c4c(c2)N(c2ccccc2C)c2c(ccc5oc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2oc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(oc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

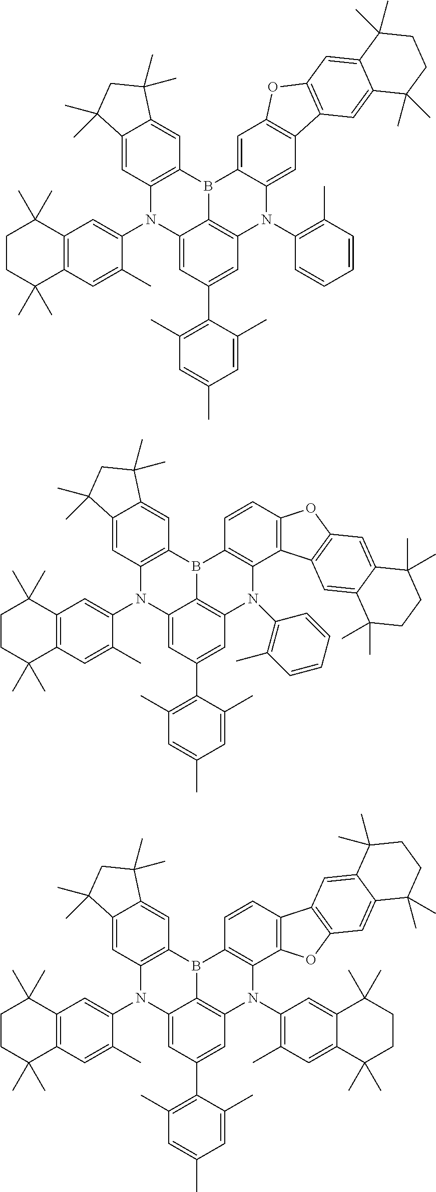 [SMILES: Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

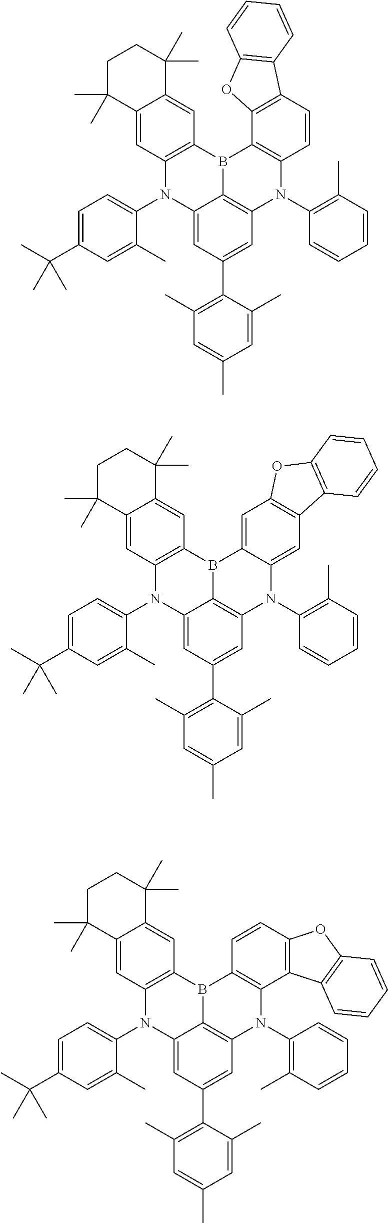 [SMILES: Cc1cc(C)c(-c2cc3c4c(c2)N(c2ccccc2C)c2ccc5c(oc6ccccc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)oc2ccccc25)c(C)c1 ; Cc1cc(C)c(-c2cc3c4c(c2)N(c2ccccc2C)c2c(ccc5oc6ccccc6c25)B4c2cc4c(cc2N3c2ccc(C(C)(C)C)cc2C)C(C)(C)CCC4(C)C)c(C)c1]

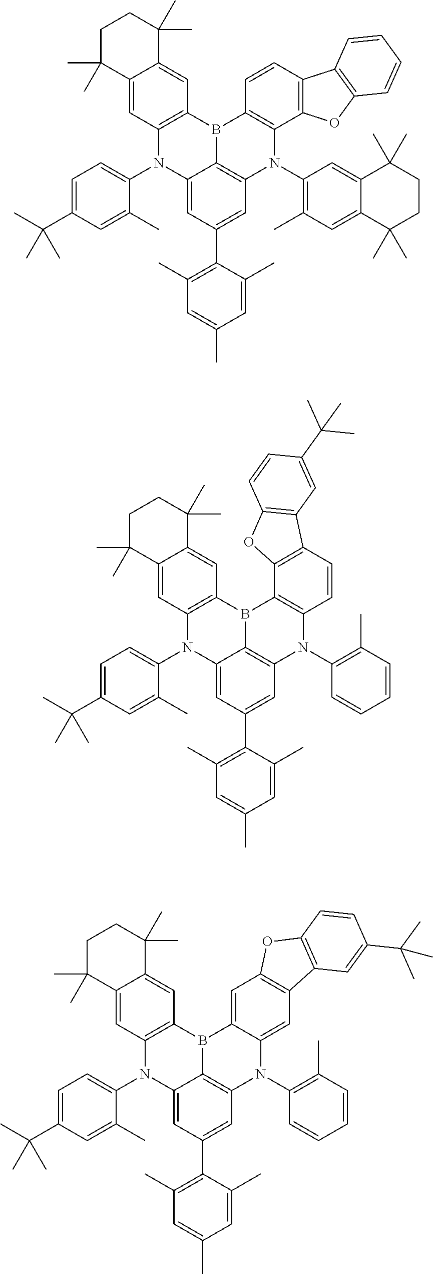 [SMILES: Cc1cc(C)c(-c2cc3c4c(c2)N(c2cc5c(cc2C)C(C)(C)CCC5(C)C)c2c(ccc5c2oc2ccccc25)B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2ccc5c(oc6ccc(C(C)(C)C)cc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)oc2ccc(C(C)(C)C)cc25)c(C)c1]

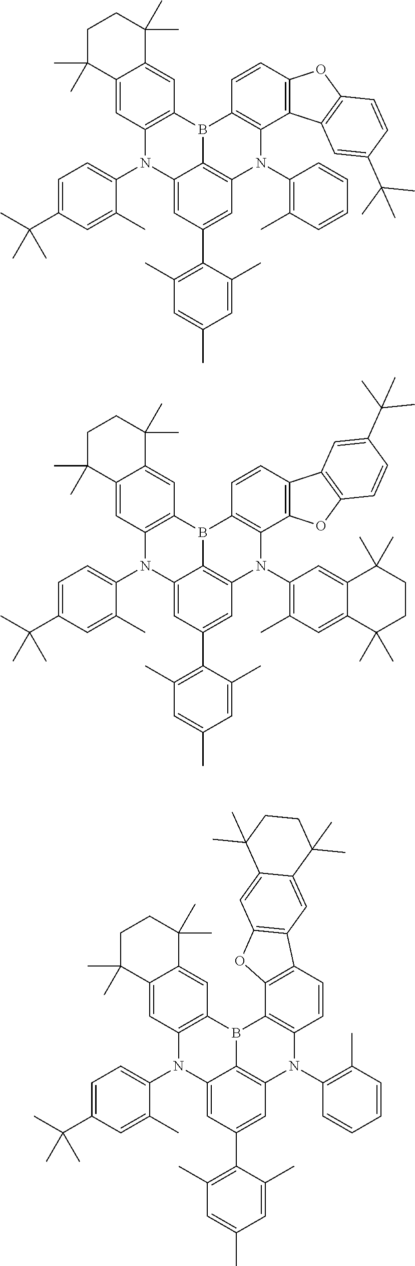

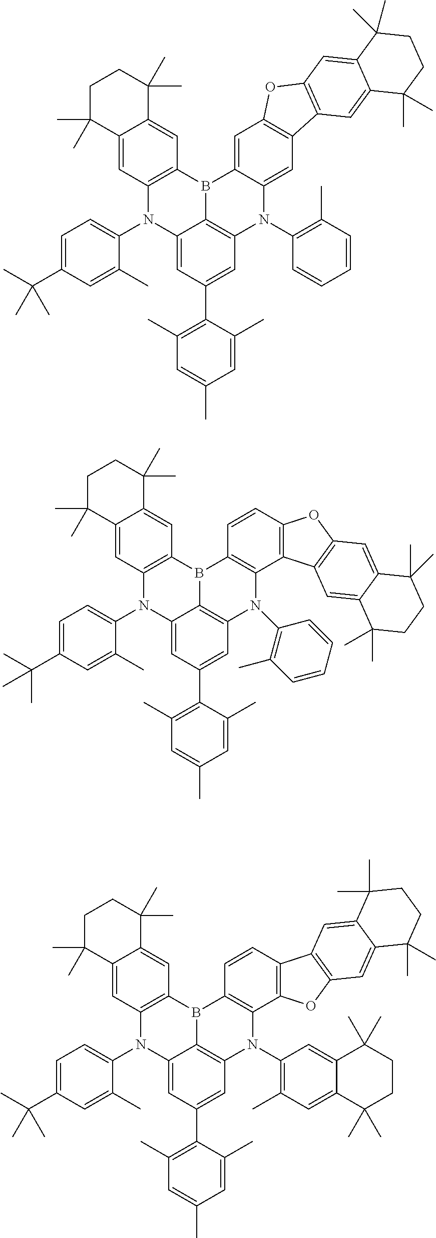

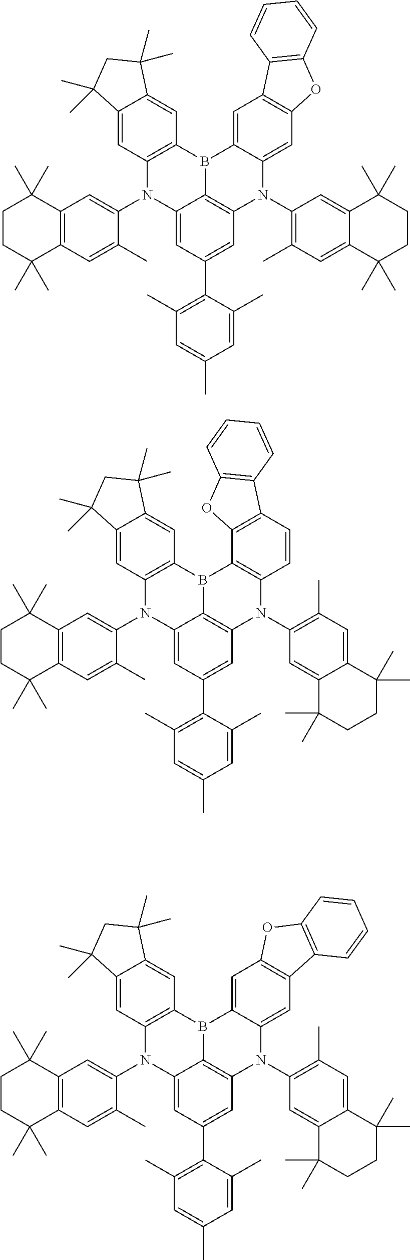

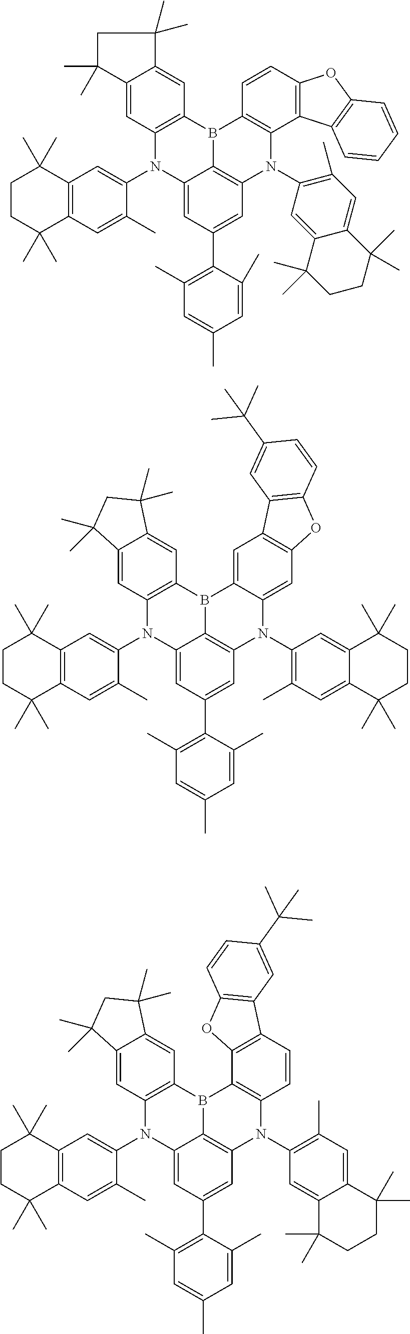

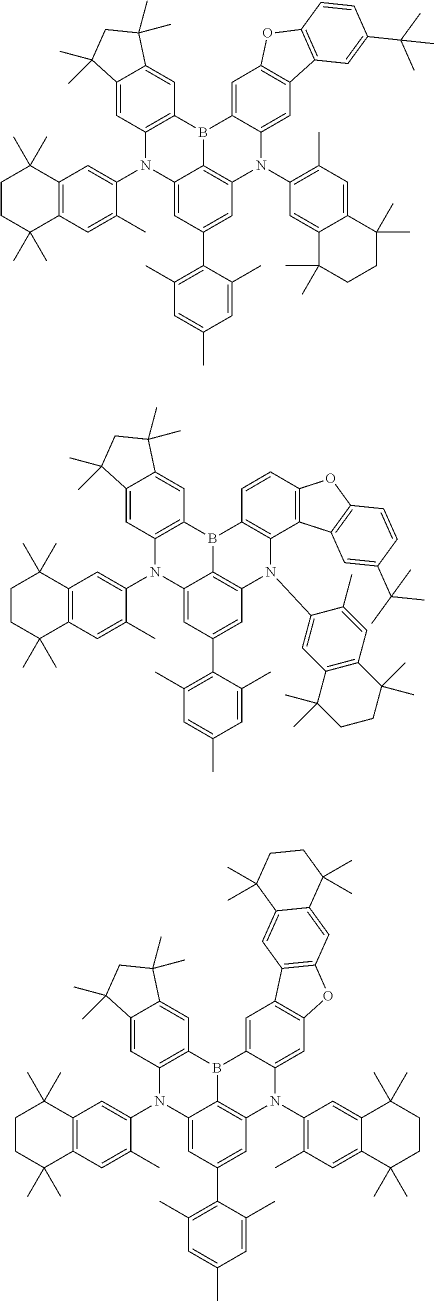 [SMILES: Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)oc2ccc(C(C)(C)C)cc25)c(C)c1 ; Cc1cc(C)c(-c2cc3c4c(c2)N(c2cc5c(cc2C)C(C)(C)CCC5(C)C)c2c(ccc5oc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5oc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

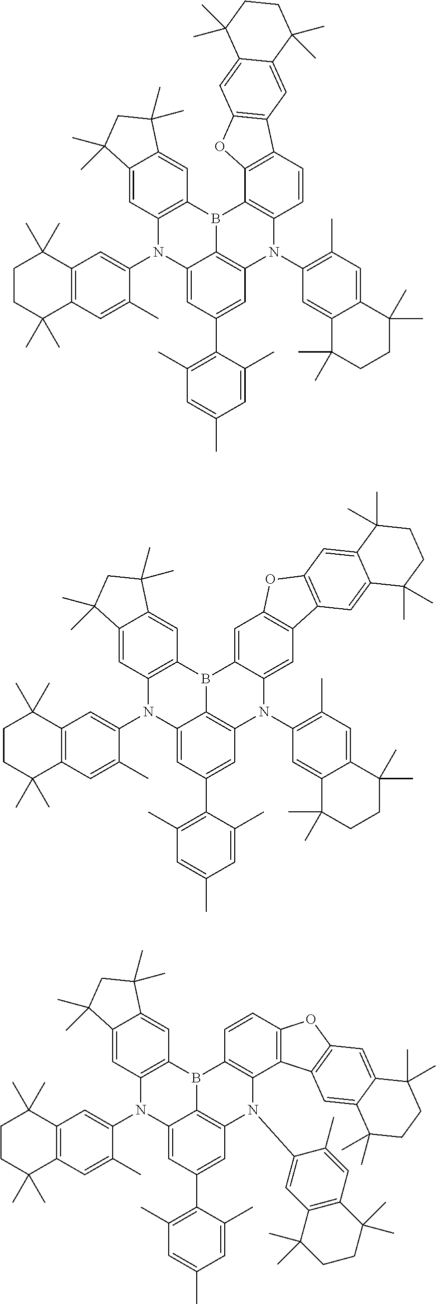 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2cc3c(cc2C)C(C)(C)CCC3(C)C)C(C)(C)CC4(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1]

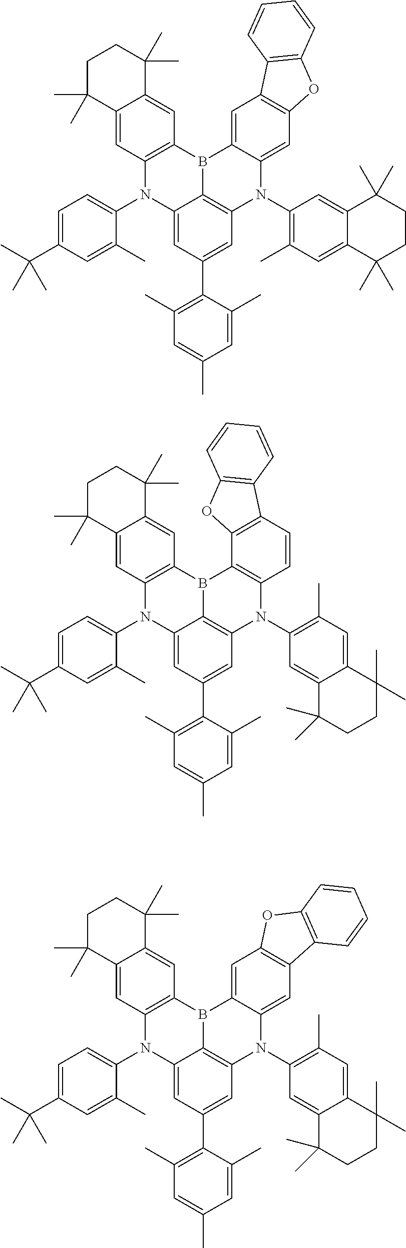

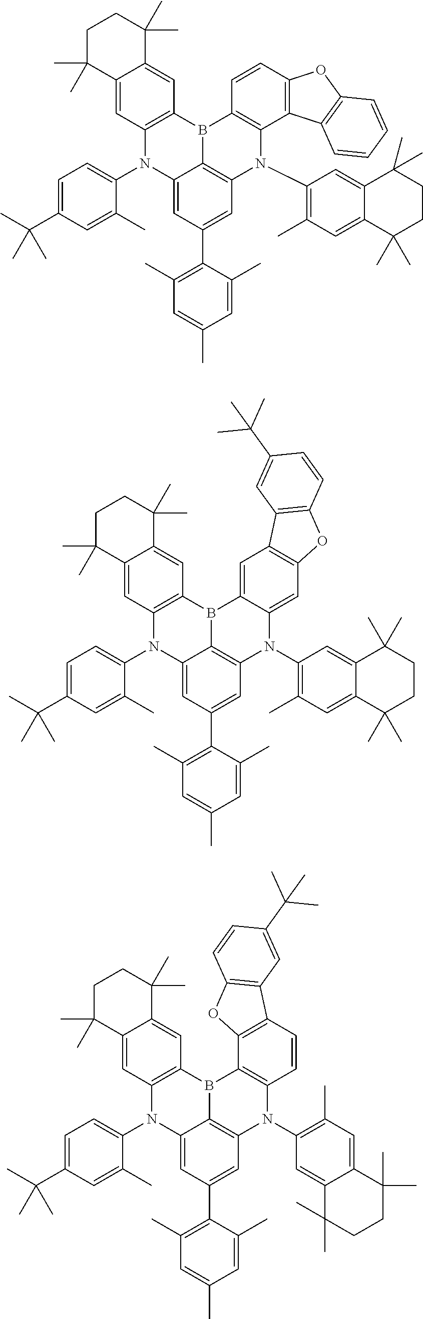

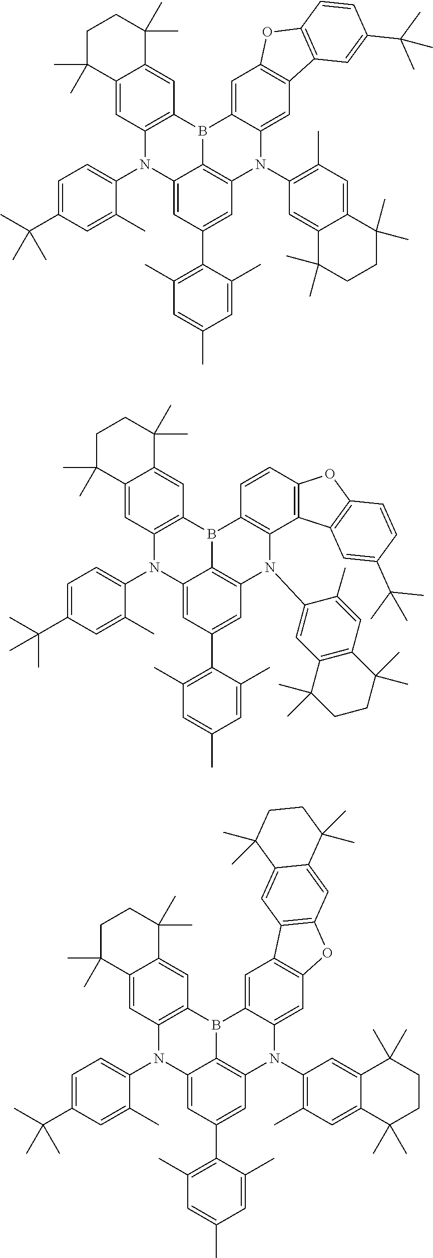

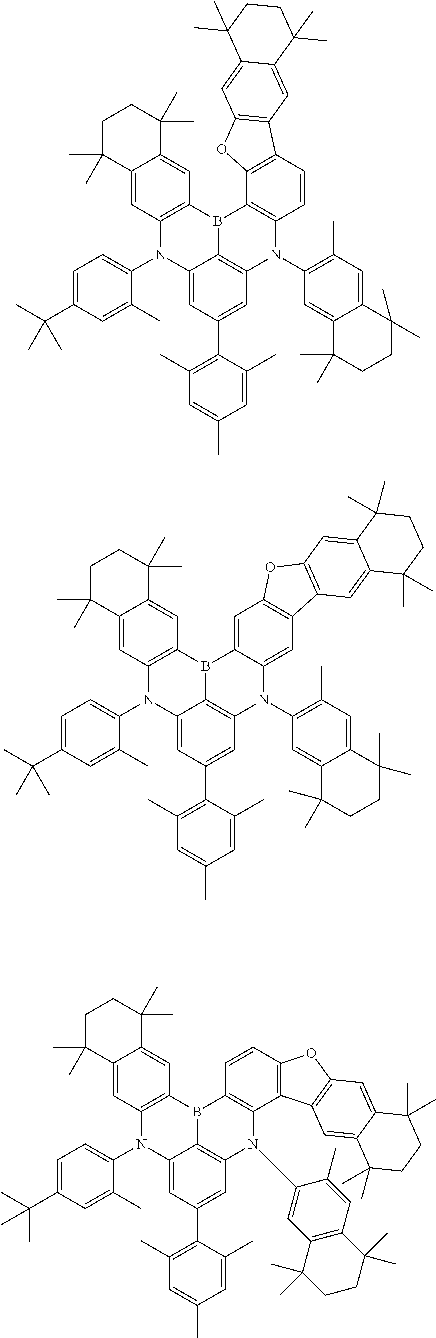

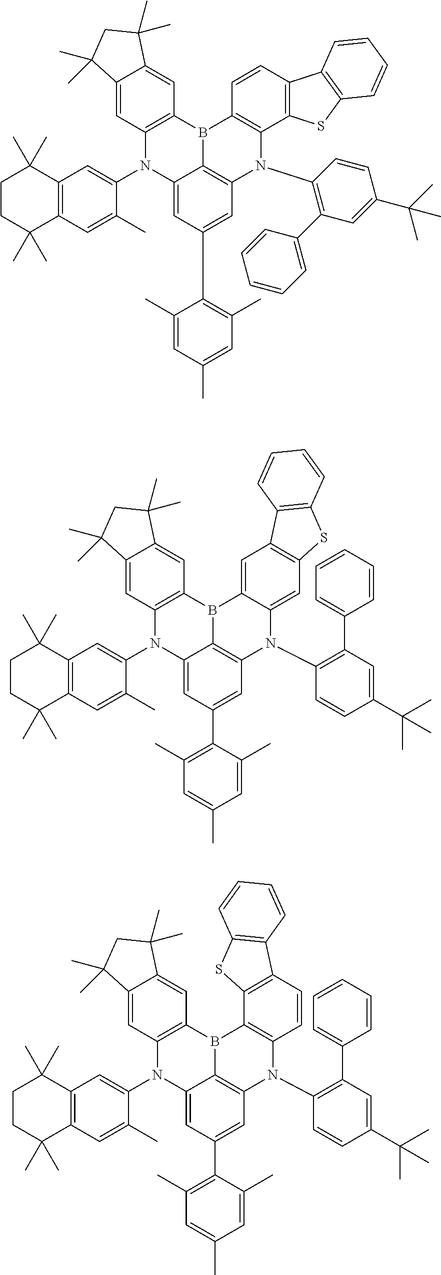

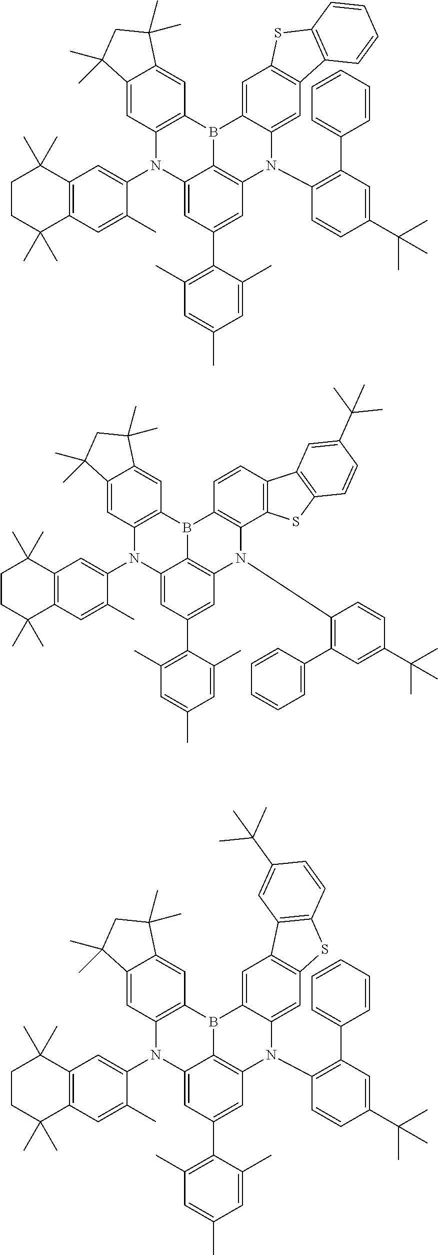 [SMILES: Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)sc2ccccc25)c(C)c1 ; Cc1cc(C)c(-c2cc3c4c(c2)N(c2ccc(C(C)(C)C)cc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1]

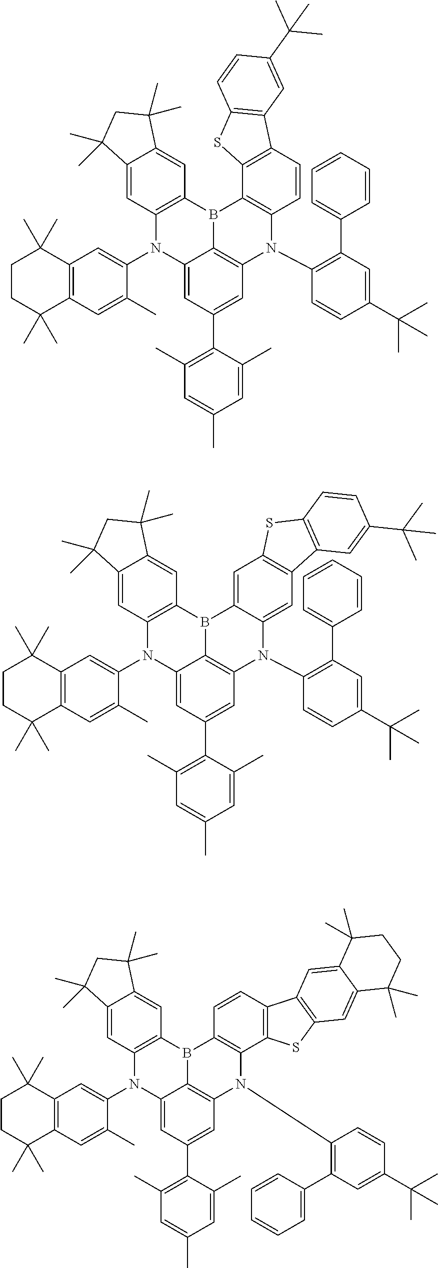 [SMILES: Cc1cc(C)c(-c2cc3c4c(c2)N(c2ccc(C(C)(C)C)cc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)sc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

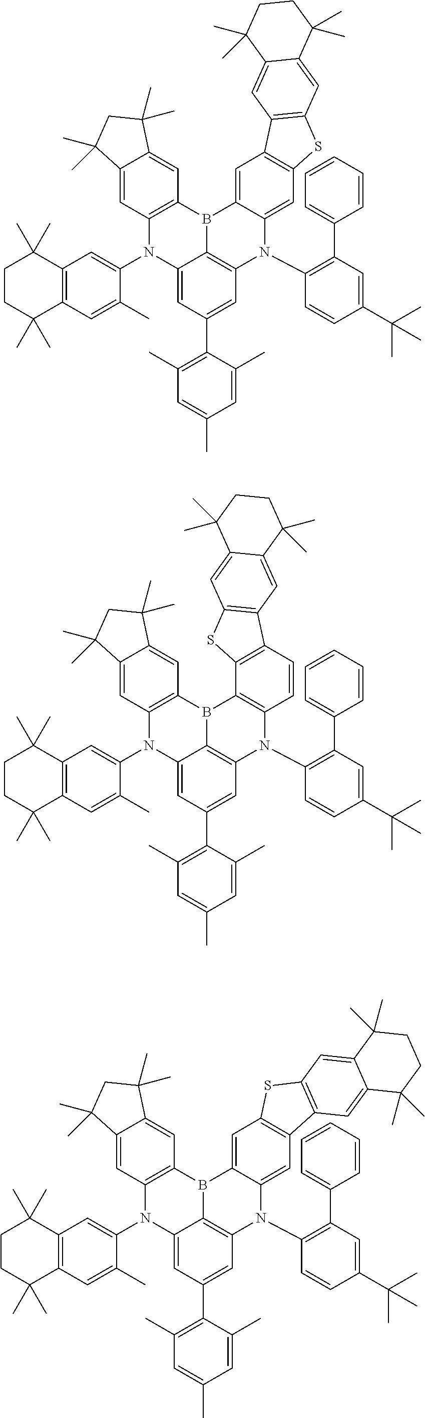 [SMILES: Cc1cc(C)c(-c2cc3c4c(c2)N(c2ccc(C(C)(C)C)cc2-c2ccccc2)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1 ; Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1]

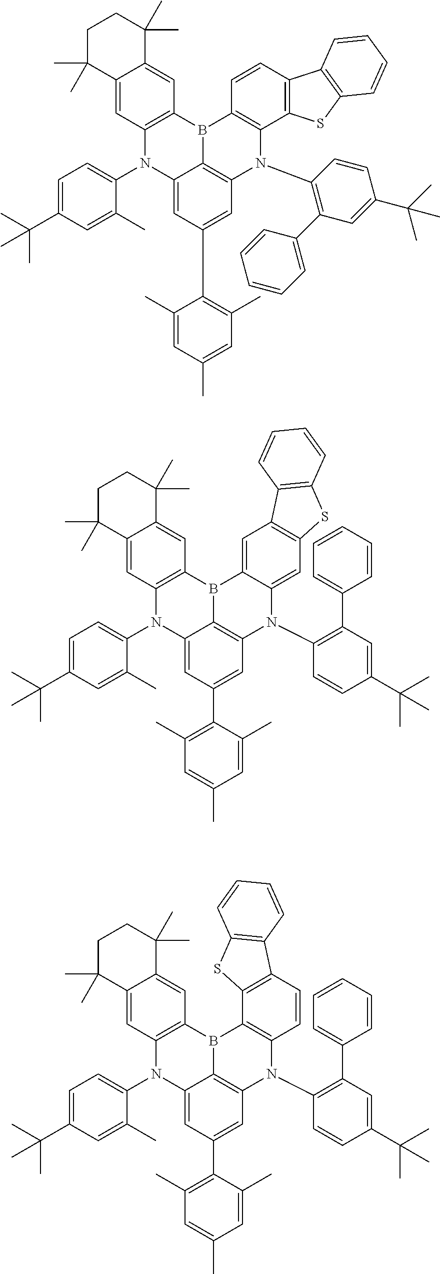

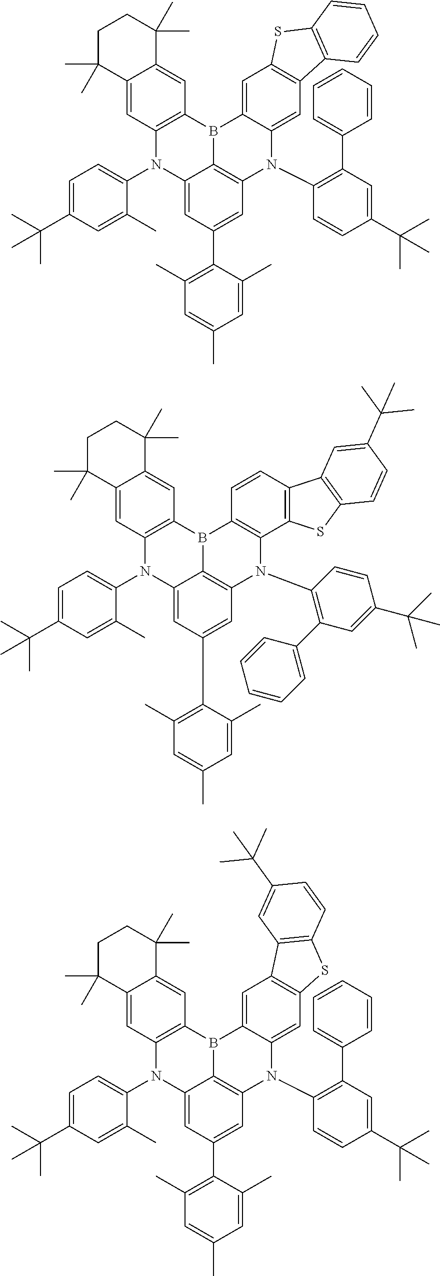

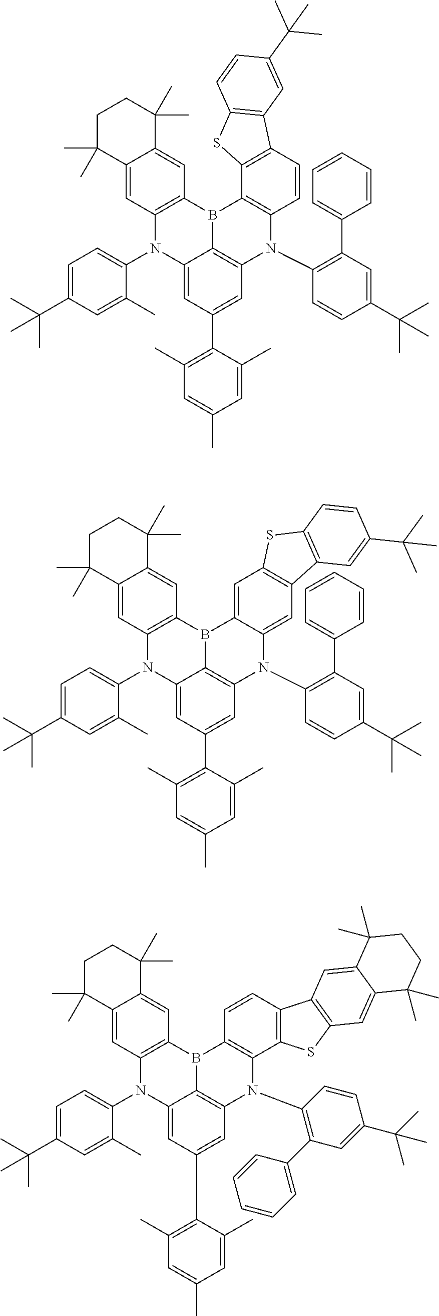

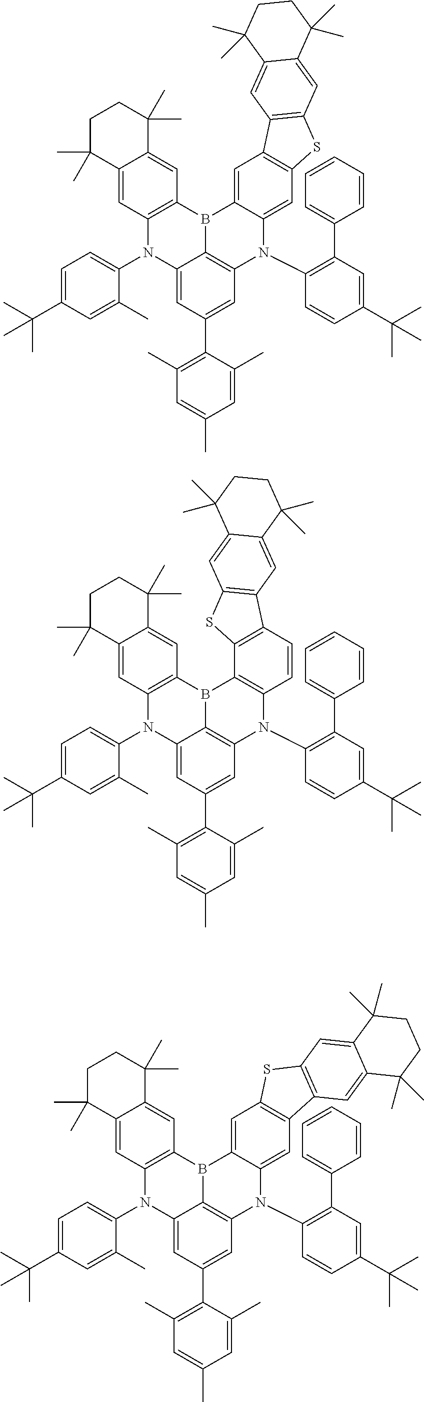

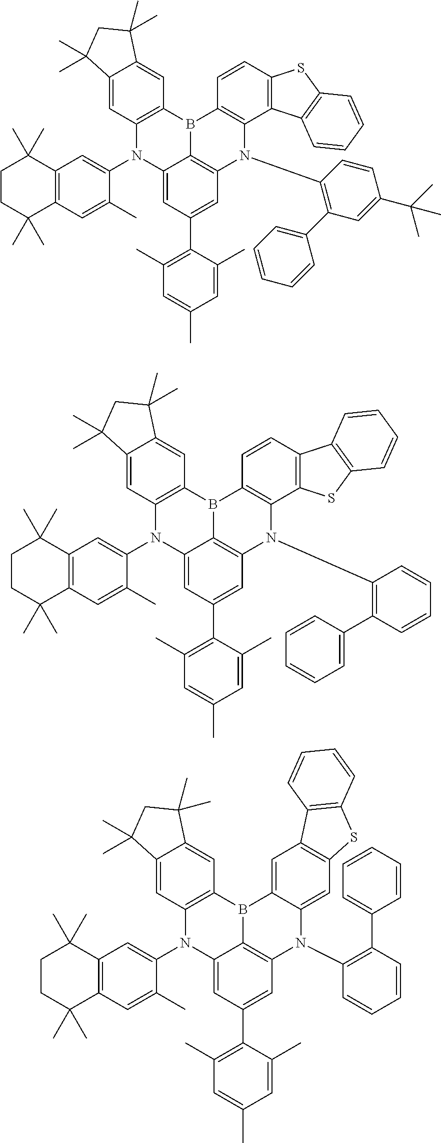

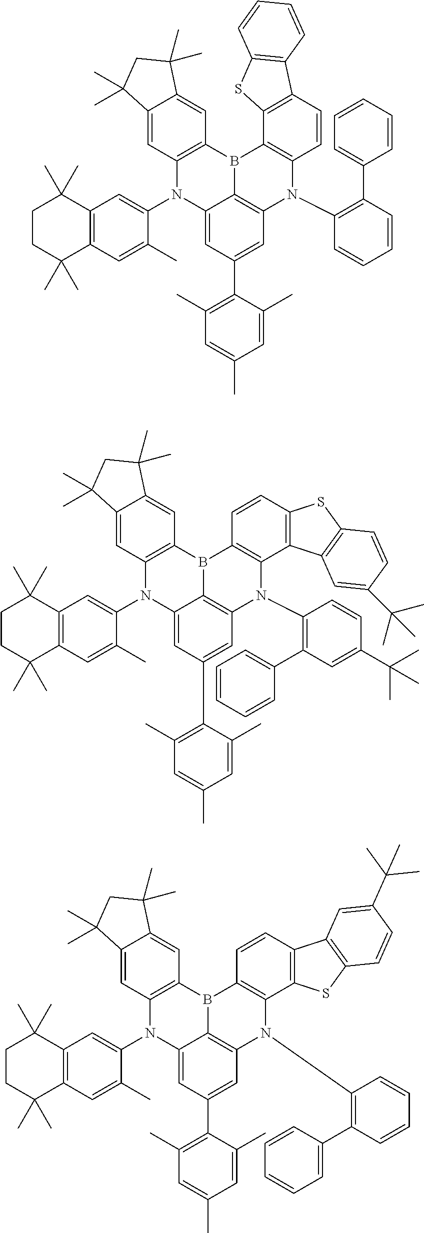 [SMILES: Cc1cc(C)c(-c2cc3c4c(c2)N(c2ccccc2-c2ccccc2)c2ccc5c(sc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2c(ccc5sc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1]

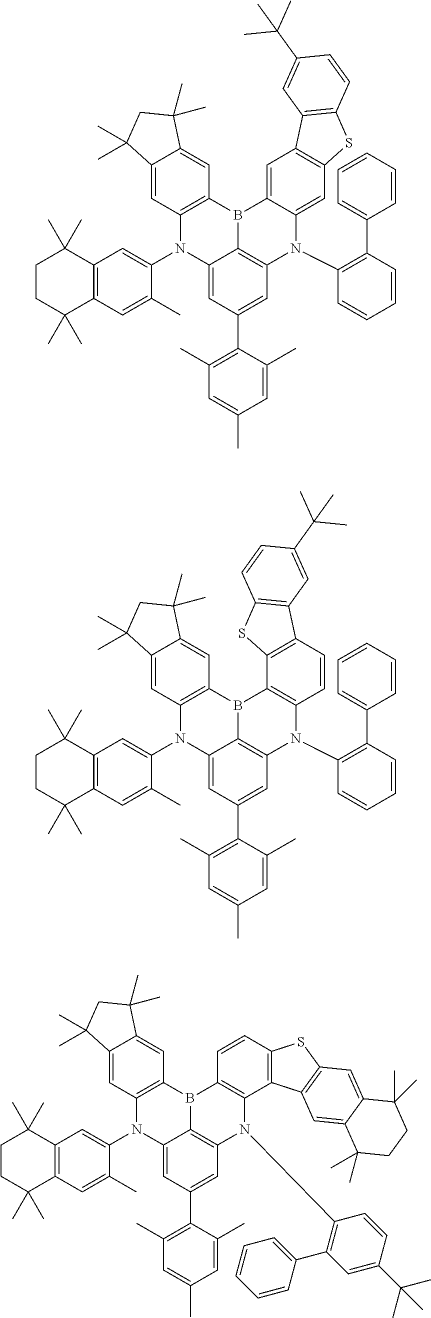 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1]

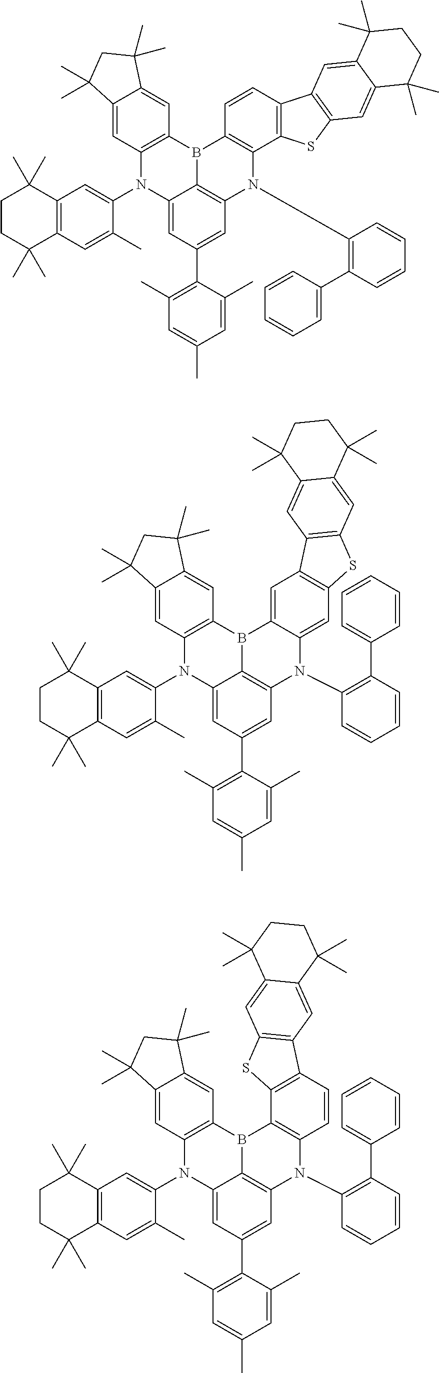 [SMILES: Cc1cc(C)c(-c2cc3c4c(c2)N(c2ccccc2-c2ccccc2)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1 ; Cc1cc(C)c(-c2cc3c4c(c2)N(c2ccccc2-c2ccccc2)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

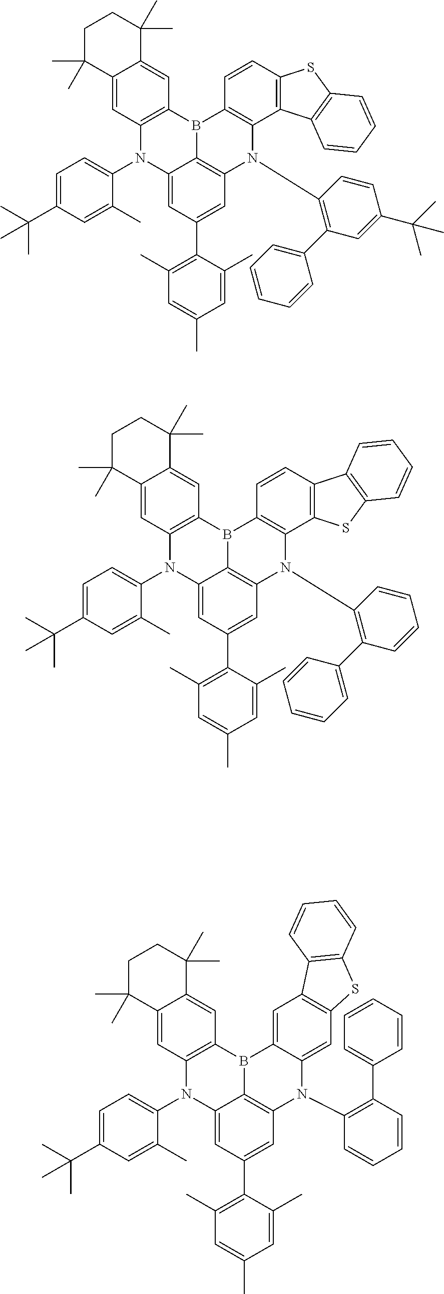

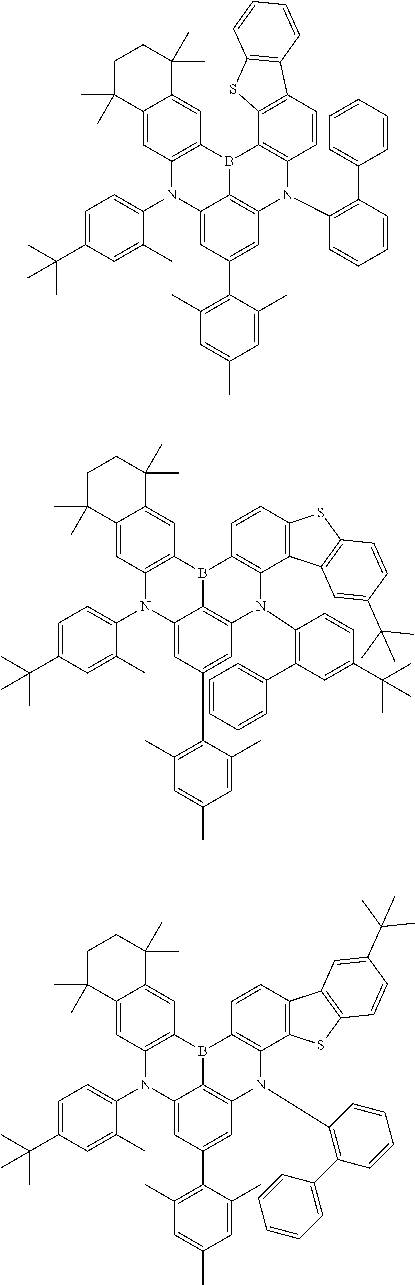

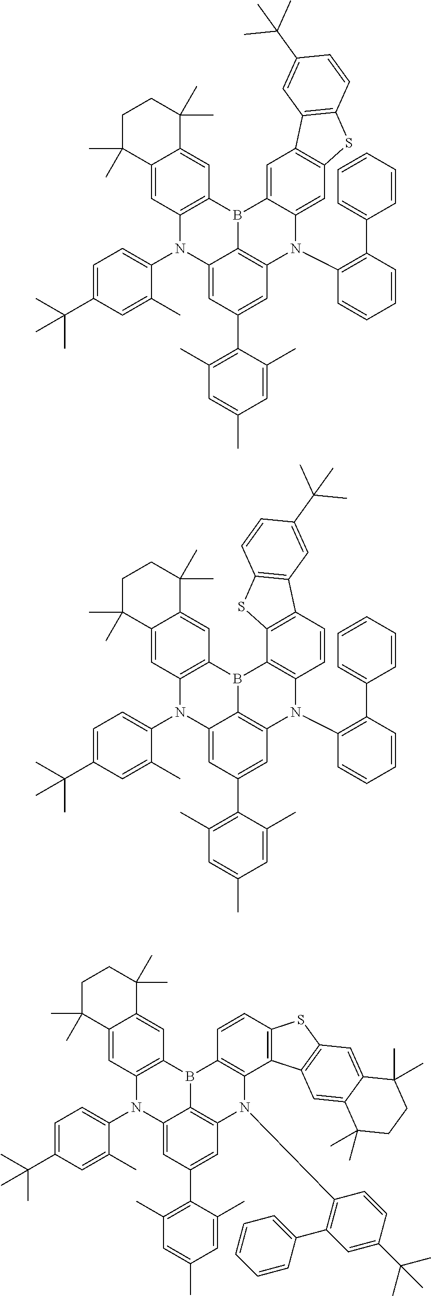 [SMILES: Cc1cc(C)c(-c2cc3c4c(c2)N(c2ccccc2-c2ccccc2)c2cc5sc6ccc(C(C)(C)C)cc6c5cc2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2-c2ccccc2)c2ccc5c(sc6ccc(C(C)(C)C)cc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc(C(C)(C)C)cc2C)C(C)(C)CCC4(C)C)c(C)c1]

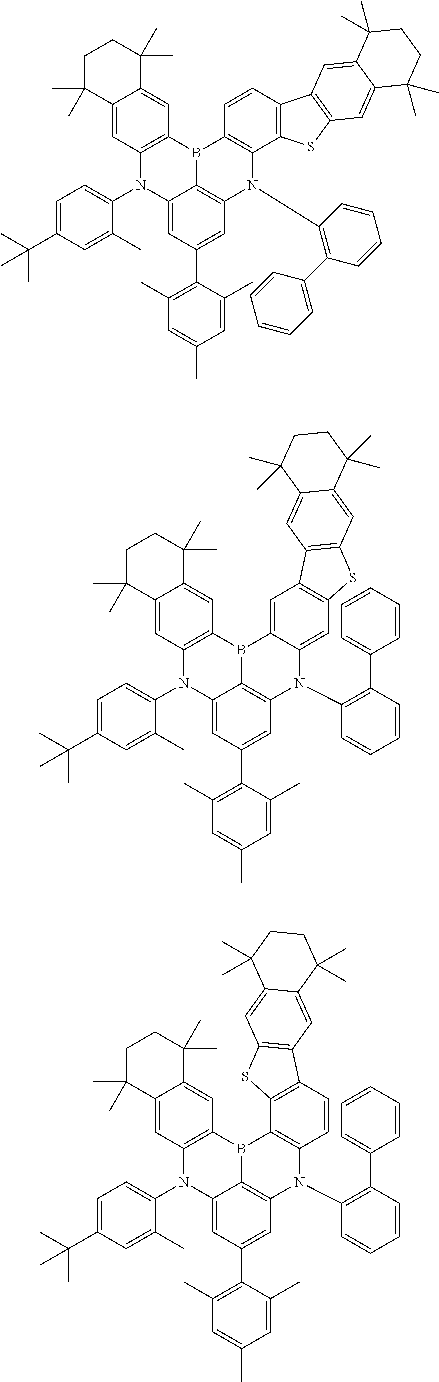

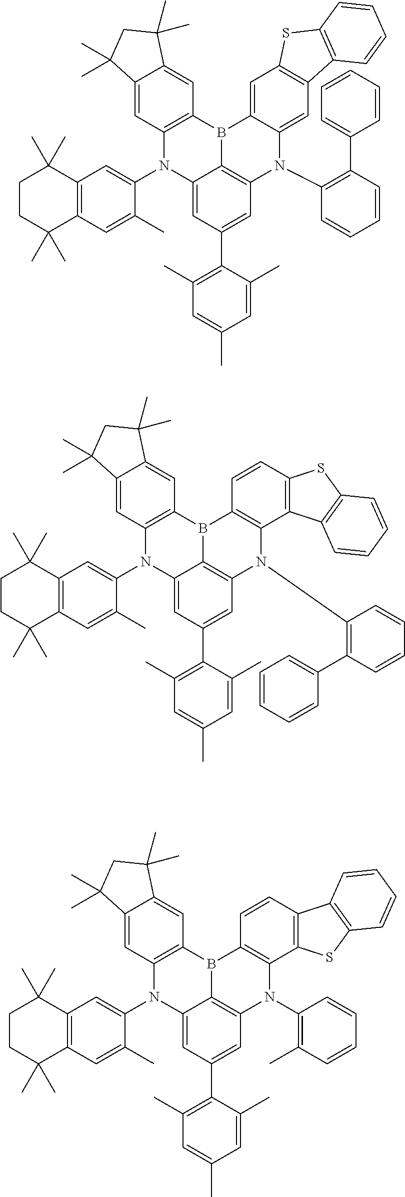 [SMILES: Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)sc2ccccc25)c(C)c1 ; Cc1cc(C)c(-c2cc3c4c(c2)N(c2ccccc2-c2ccccc2)c2c(ccc5sc6ccccc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2sc2ccccc25)B4c2cc4c(cc2N3c2cc3c(cc2C)C(C)(C)CCC3(C)C)C(C)(C)CC4(C)C)c(C)c1]

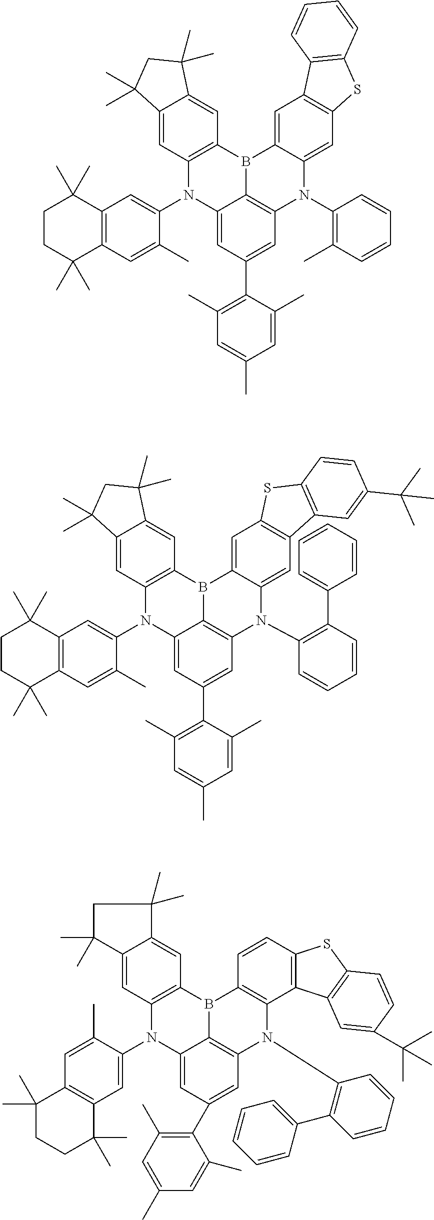

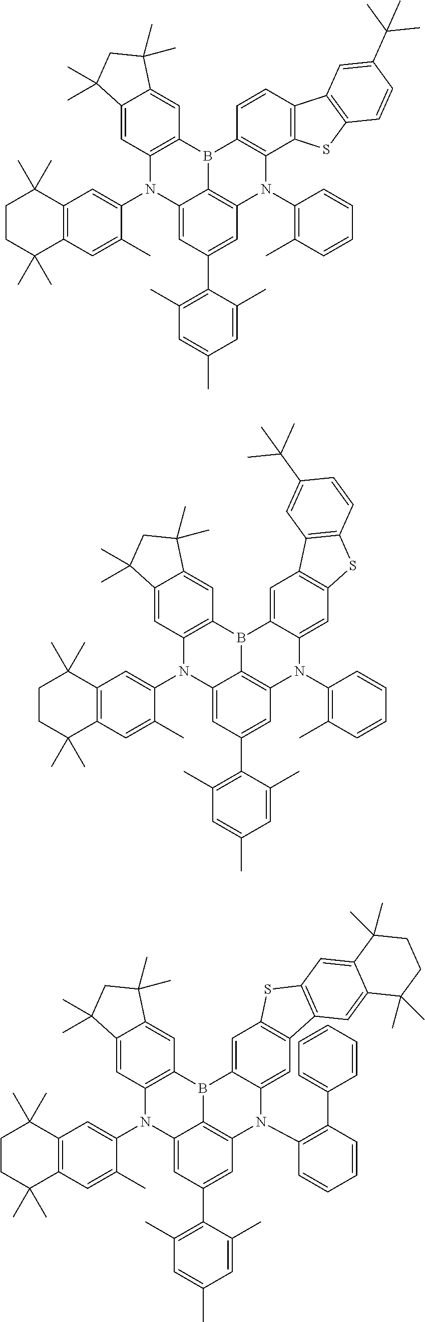 [SMILES: Cc1cc(C)c(-c2cc3c4c(c2)N(c2ccccc2C)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5sc6ccc(C(C)(C)C)cc6c5cc2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2-c2ccccc2)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1]

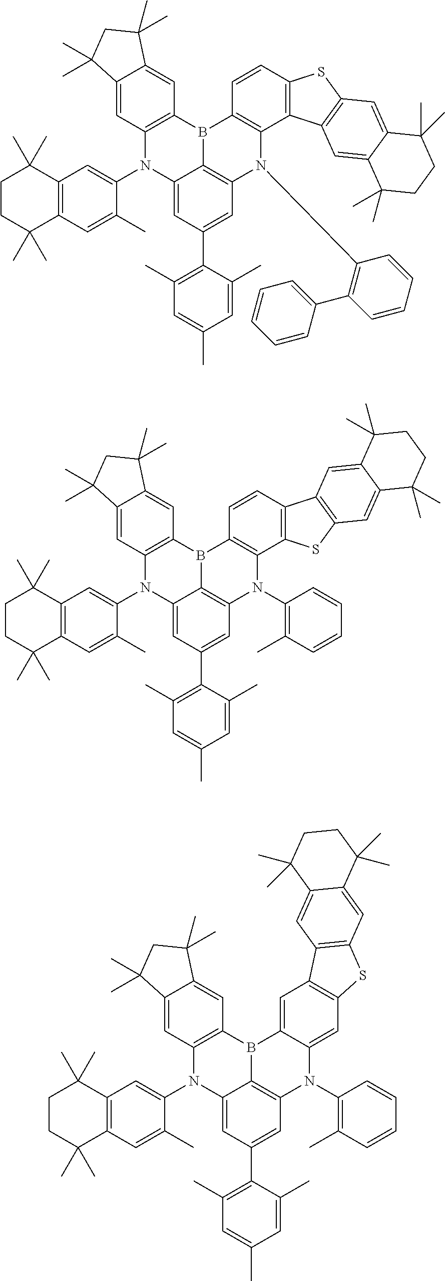 [SMILES: Cc1cc(C)c(-c2cc3c4c(c2)N(c2ccccc2-c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5sc6cc7c(cc6c5cc2B4c2cc4c(cc2N3c2cc3c(cc2C)C(C)(C)CCC3(C)C)C(C)(C)CC4(C)C)C(C)(C)CCC7(C)C)c(C)c1]

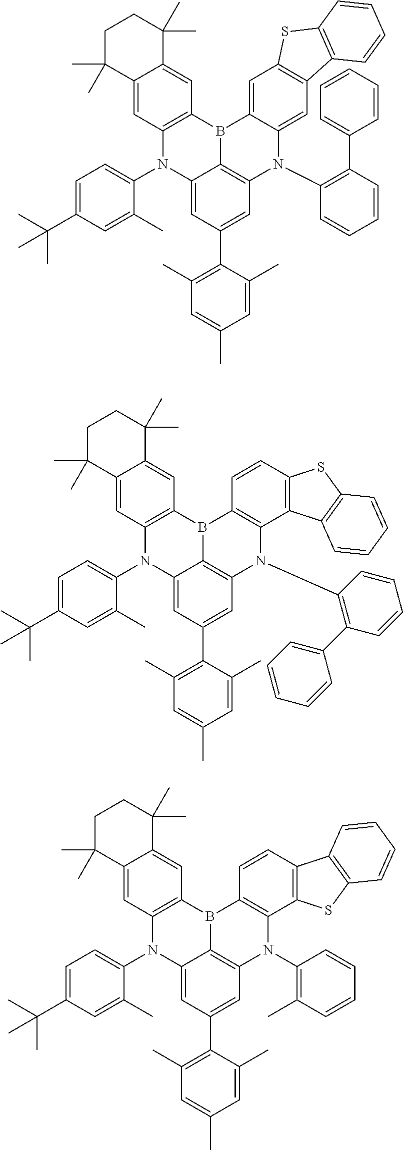

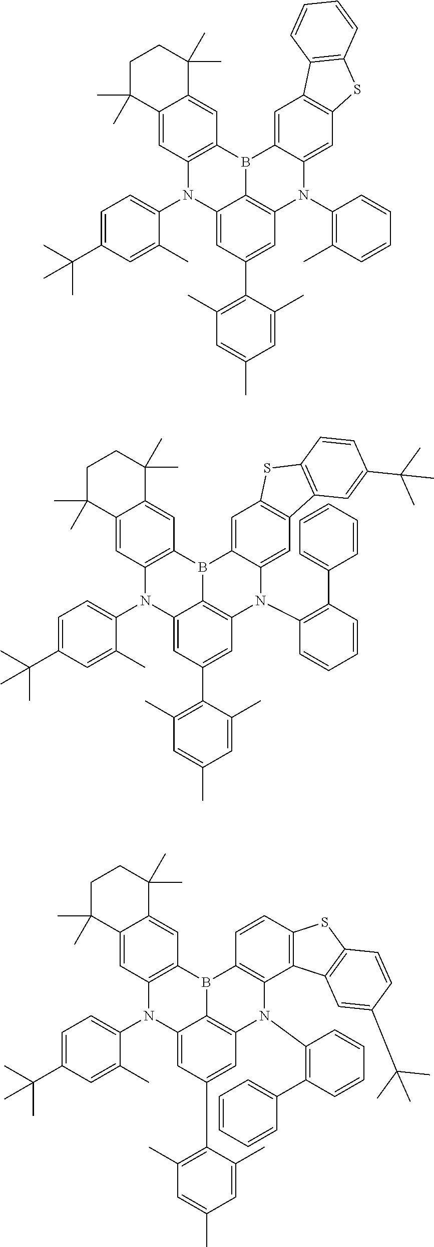

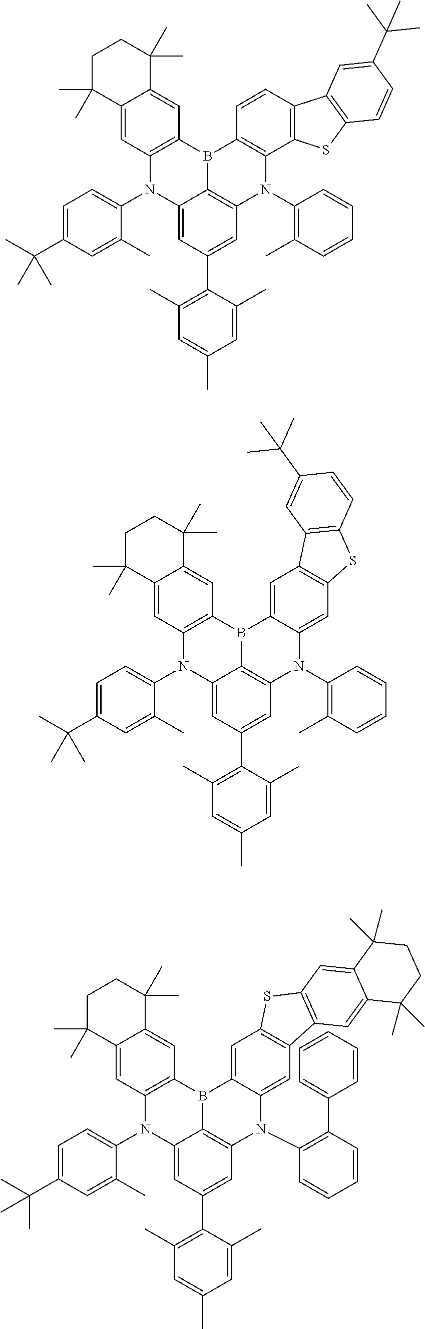

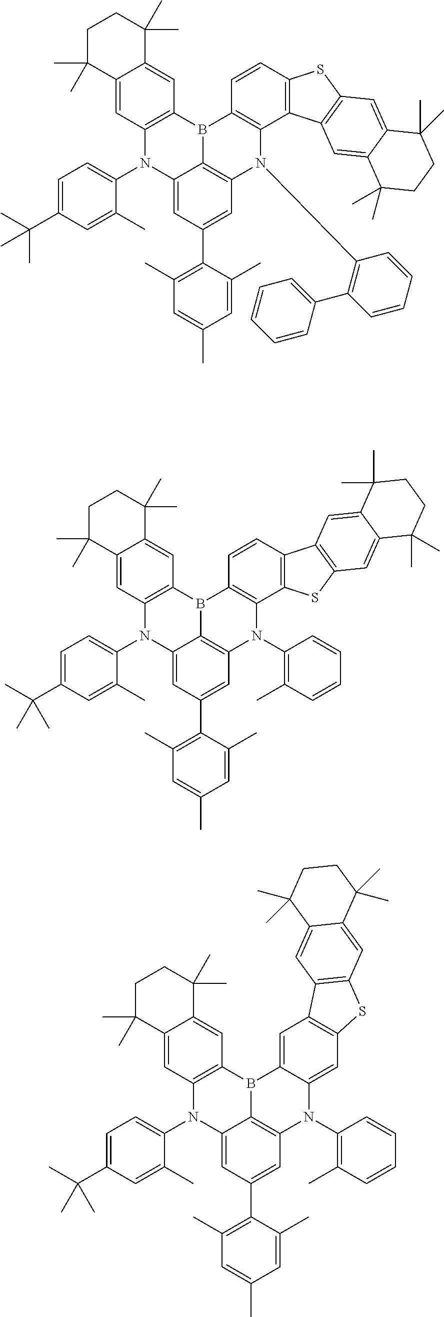

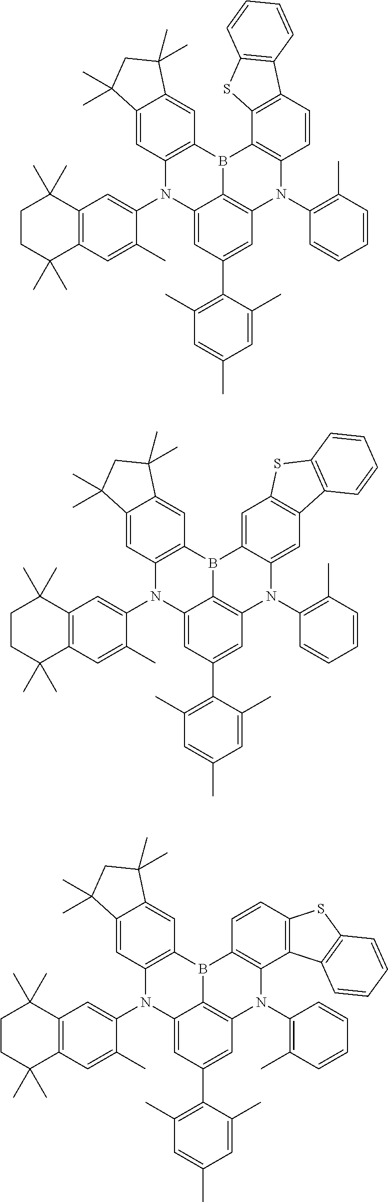 [SMILES: Cc1cc(C)c(-c2cc3c4c(c2)N(c2ccccc2C)c2ccc5c(sc6ccccc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2cc3c(cc2C)C(C)(C)CCC3(C)C)C(C)(C)CC4(C)C)c(C)c1]

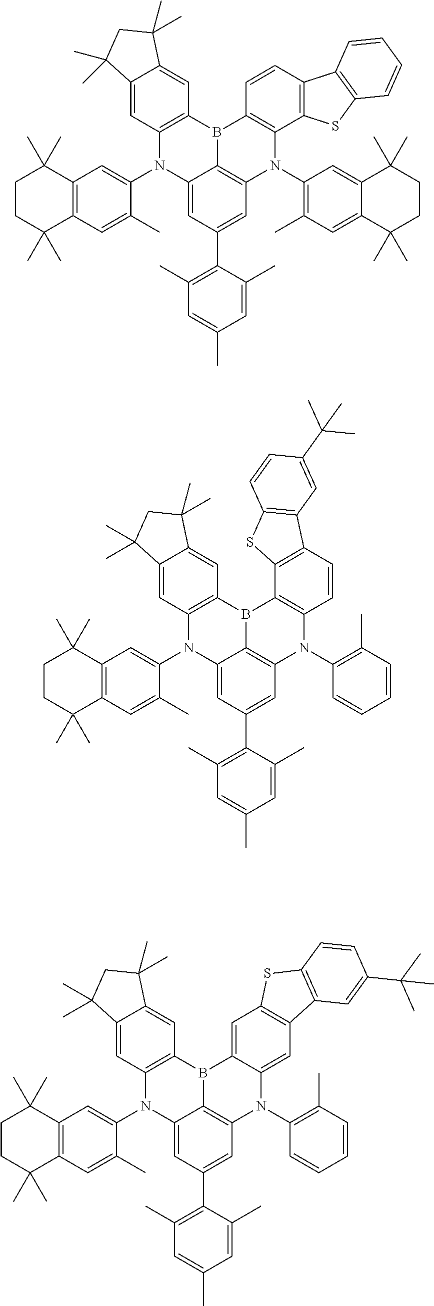 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)sc2ccc(C(C)(C)C)cc25)c(C)c1]

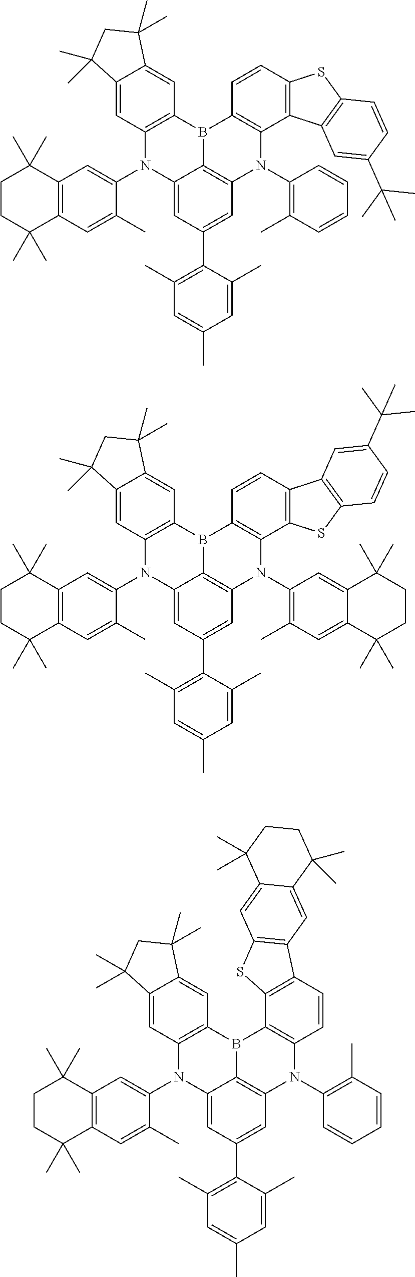 [SMILES: Cc1cc(C)c(-c2cc3c4c(c2)N(c2ccccc2C)c2c(ccc5sc6ccc(C(C)(C)C)cc6c25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2sc2ccc(C(C)(C)C)cc25)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2ccccc2C)c2ccc5c(sc6cc7c(cc65)C(C)(C)CCC7(C)C)c2B4c2cc4c(cc2N3c2cc3c(cc2C)C(C)(C)CCC3(C)C)C(C)(C)CC4(C)C)c(C)c1]

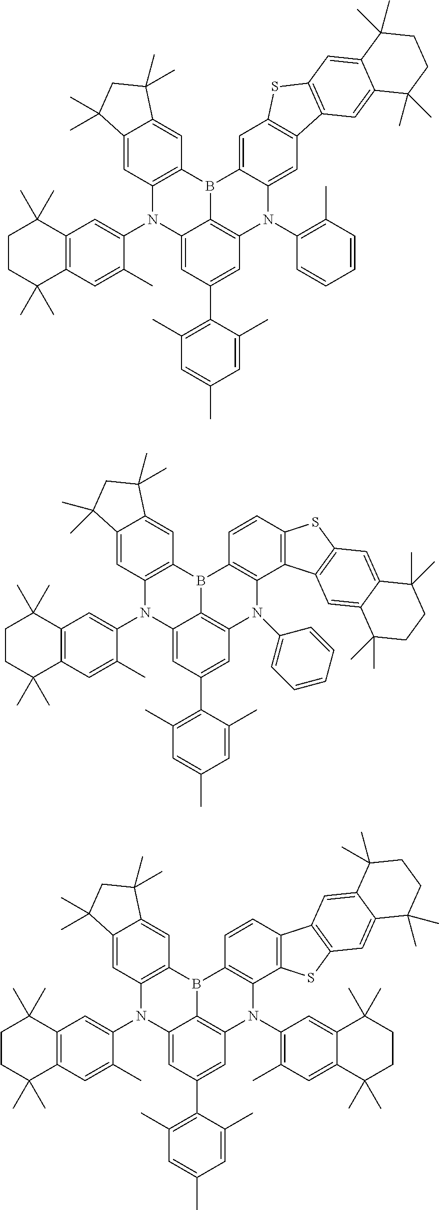 [SMILES: Cc1cc(C)c(-c2cc3c4c(c2)N(c2ccccc2C)c2cc5c(cc2B4c2cc4c(cc2N3c2cc3c(cc2C)C(C)(C)CCC3(C)C)C(C)(C)CC4(C)C)sc2cc3c(cc25)C(C)(C)CCC3(C)C)c(C)c1 ; Cc1cc(C)c(-c2cc3c4c(c2)N(c2ccccc2)c2c(ccc5sc6cc7c(cc6c25)C(C)(C)CCC7(C)C)B4c2cc4c(cc2N3c2cc3c(cc2C)C(C)(C)CCC3(C)C)C(C)(C)CC4(C)C)c(C)c1 ; Cc1cc(C)c(-c2cc3c4c(c2)N(c2cc5c(cc2C)C(C)(C)CCC5(C)C)c2c(ccc5c2sc2cc6c(cc25)C(C)(C)CCC6(C)C)B4c2cc4c(cc2N3c2cc3c(cc2C)C(C)(C)CCC3(C)C)C(C)(C)CC4(C)C)c(C)c1]

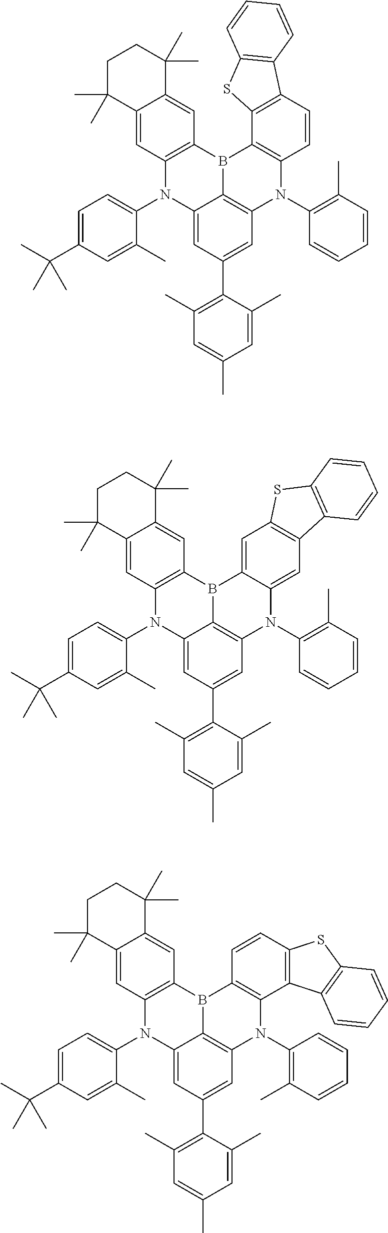 [SMILES: Cc1cc(C)c(-c2cc3c4c(c2)N(c2ccccc2C)c2ccc5c(sc6ccccc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)sc2ccccc25)c(C)c1 ; Cc1cc(C)c(-c2cc3c4c(c2)N(c2ccccc2C)c2c(ccc5sc6ccccc6c25)B4c2cc4c(cc2N3c2ccc(C(C)(C)C)cc2C)C(C)(C)CCC4(C)C)c(C)c1]

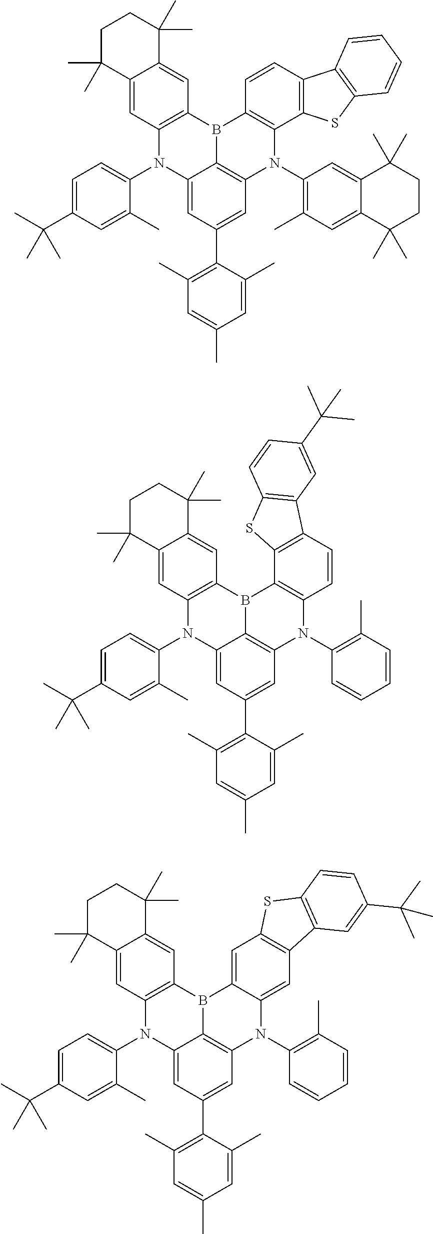 [SMILES: Cc1cc(C)c(-c2cc3c4c(c2)N(c2cc5c(cc2C)C(C)(C)CCC5(C)C)c2c(ccc5c2sc2ccccc25)B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2ccc5c(sc6ccc(C(C)(C)C)cc65)c2B4c2cc4c(cc2N3c2ccc(C(C)(C)C)cc2C)C(C)(C)CCC4(C)C)c(C)c1 ; Cc1cc(C)c(-c2cc3c4c(c2)N(c2ccccc2C)c2cc5c(cc2B4c2cc4c(cc2N3c2ccc(C(C)(C)C)cc2C)C(C)(C)CCC4(C)C)sc2ccc(C(C)(C)C)cc25)c(C)c1]

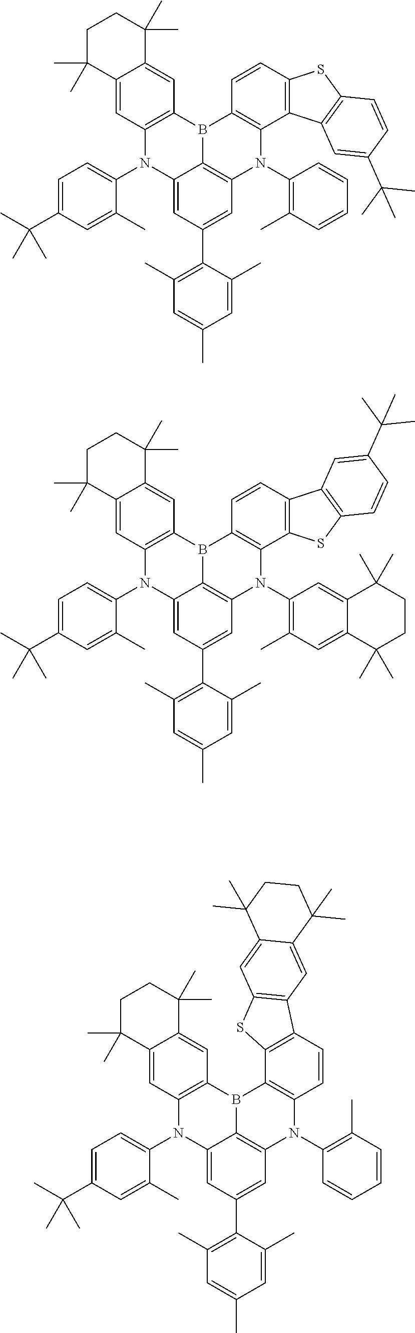

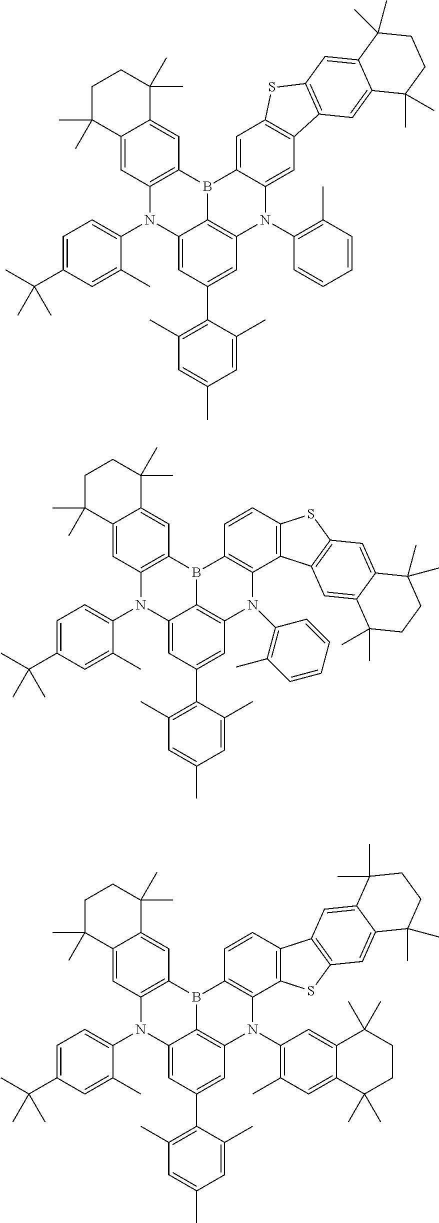

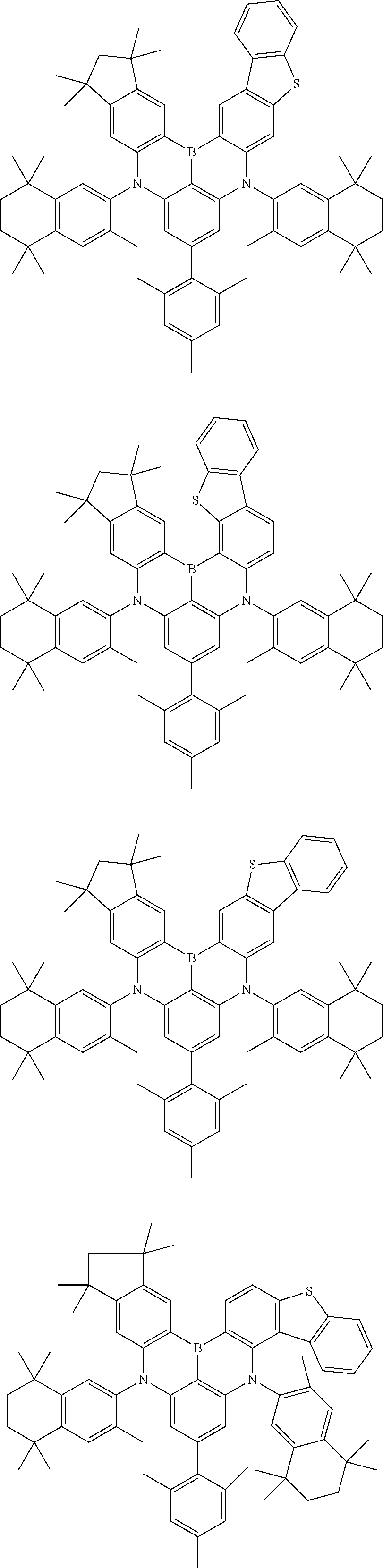

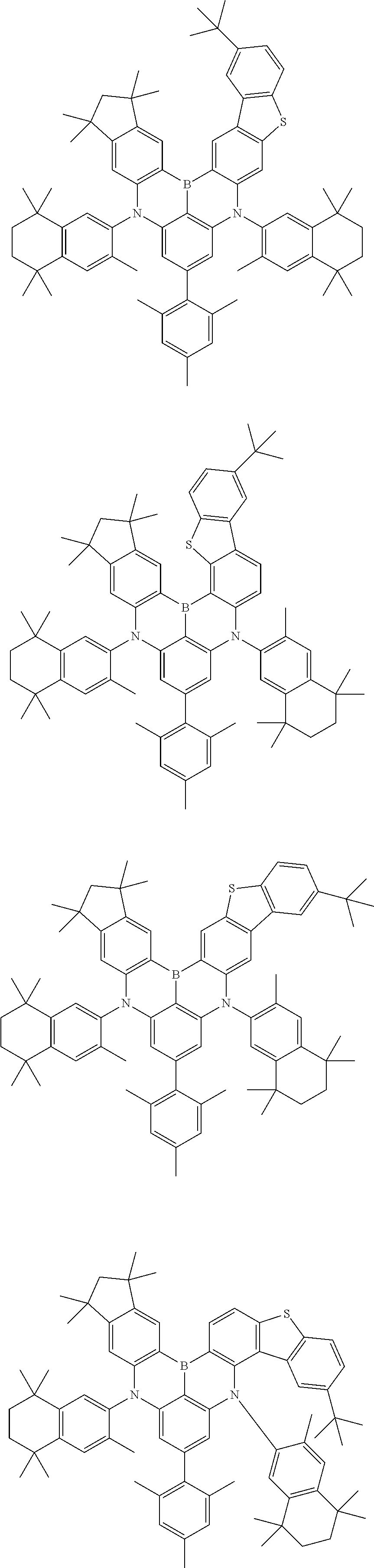

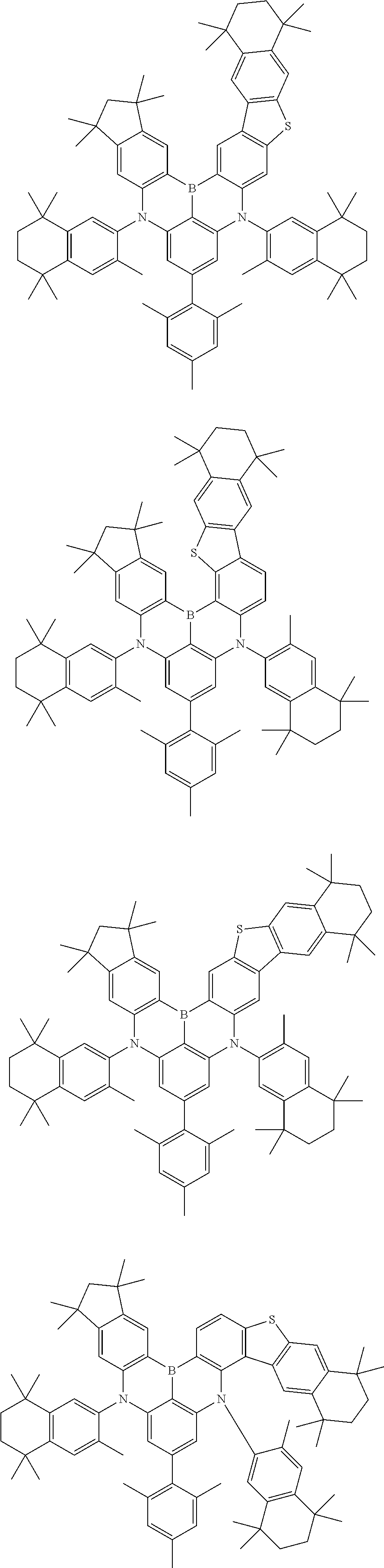

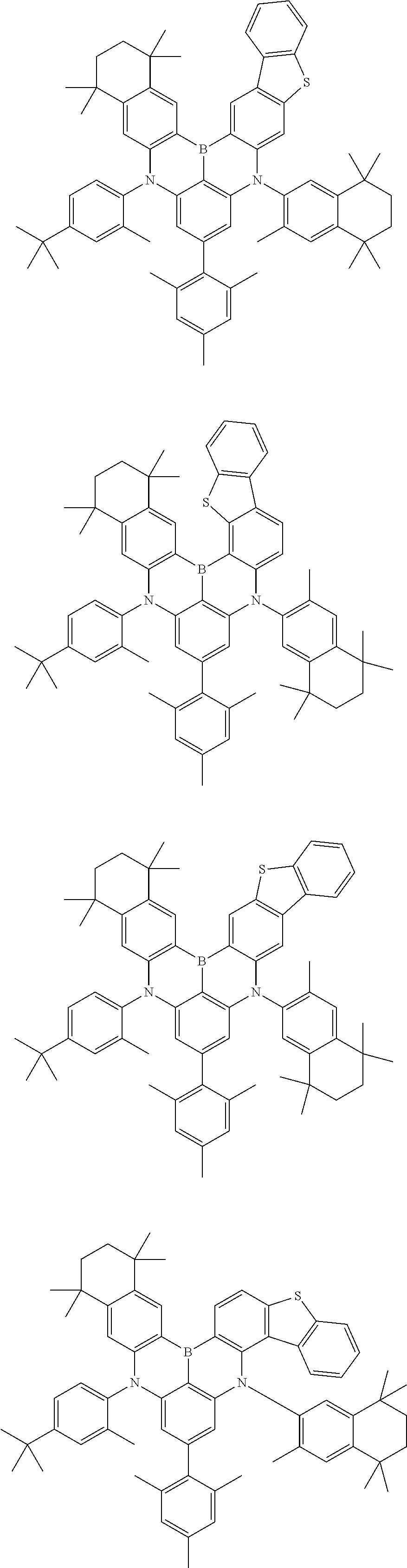

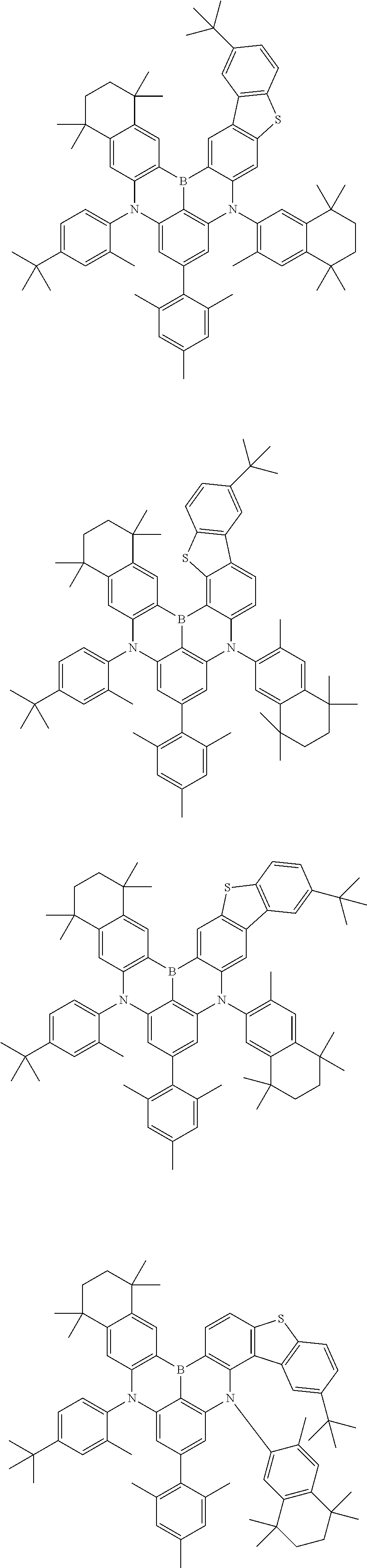

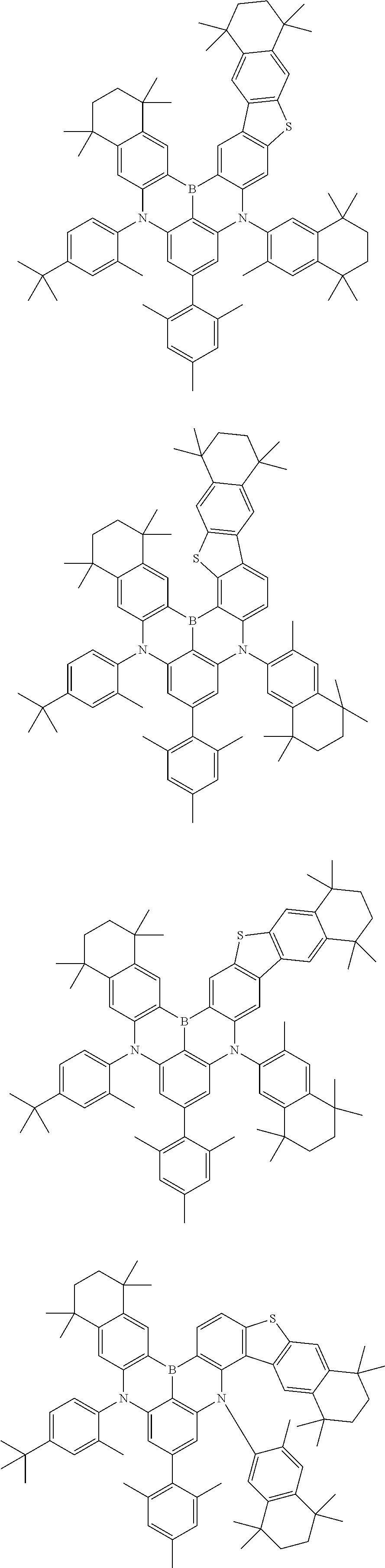

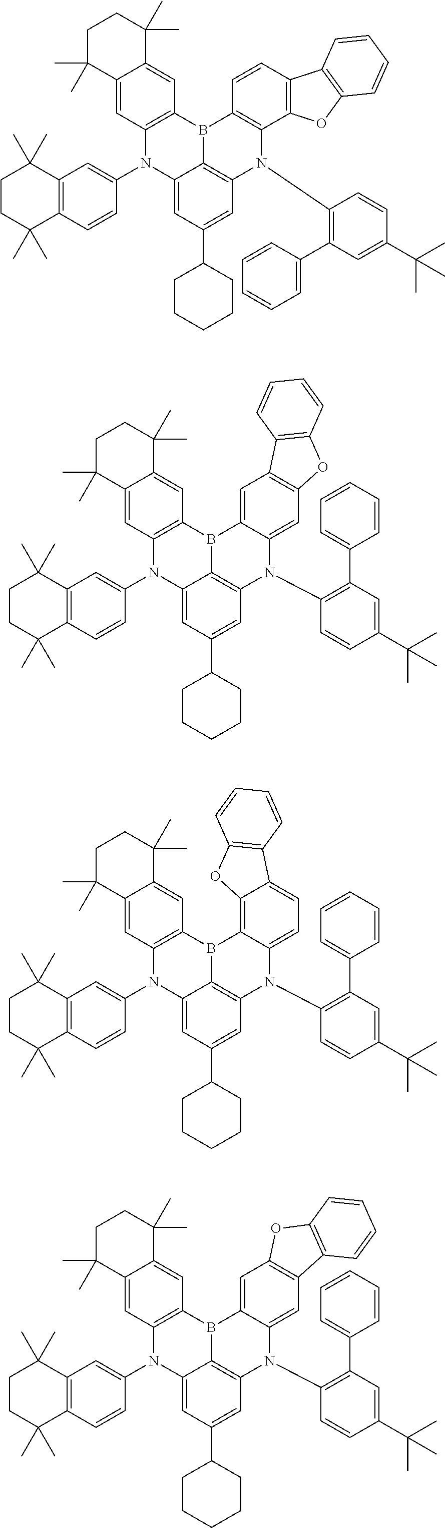

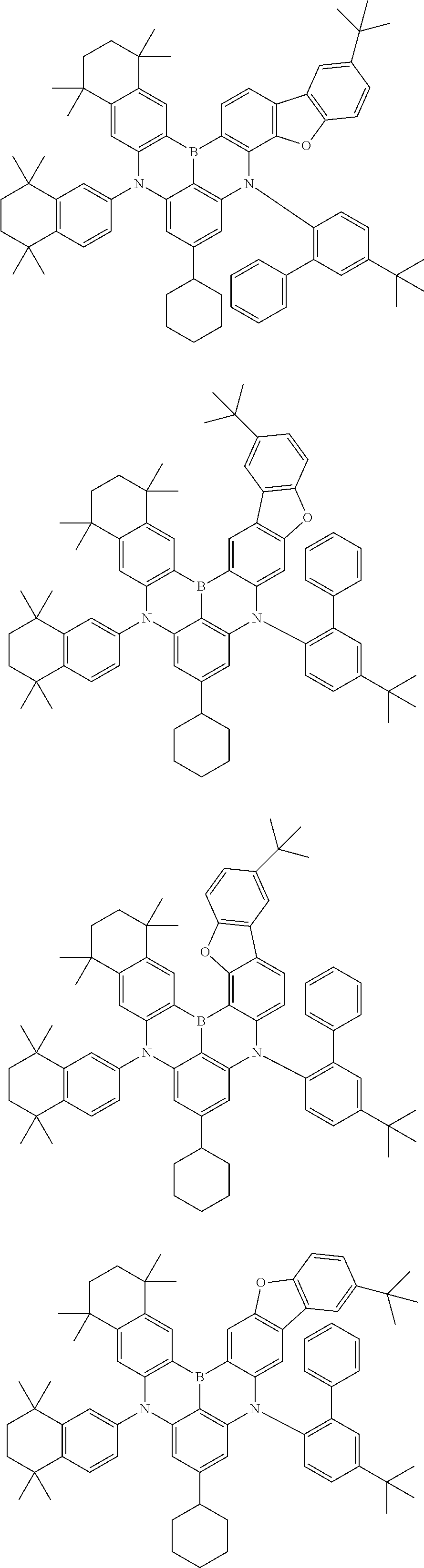

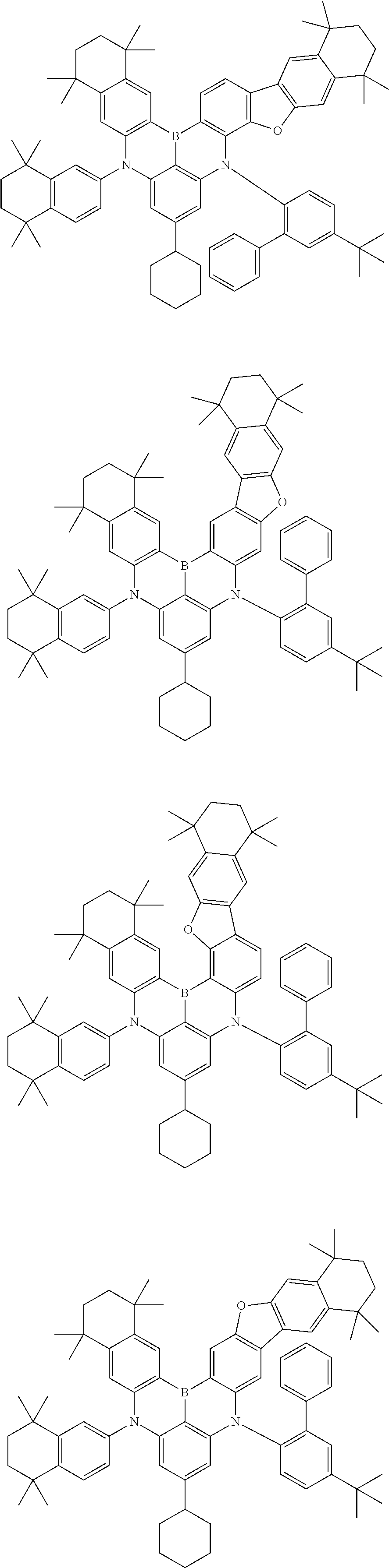

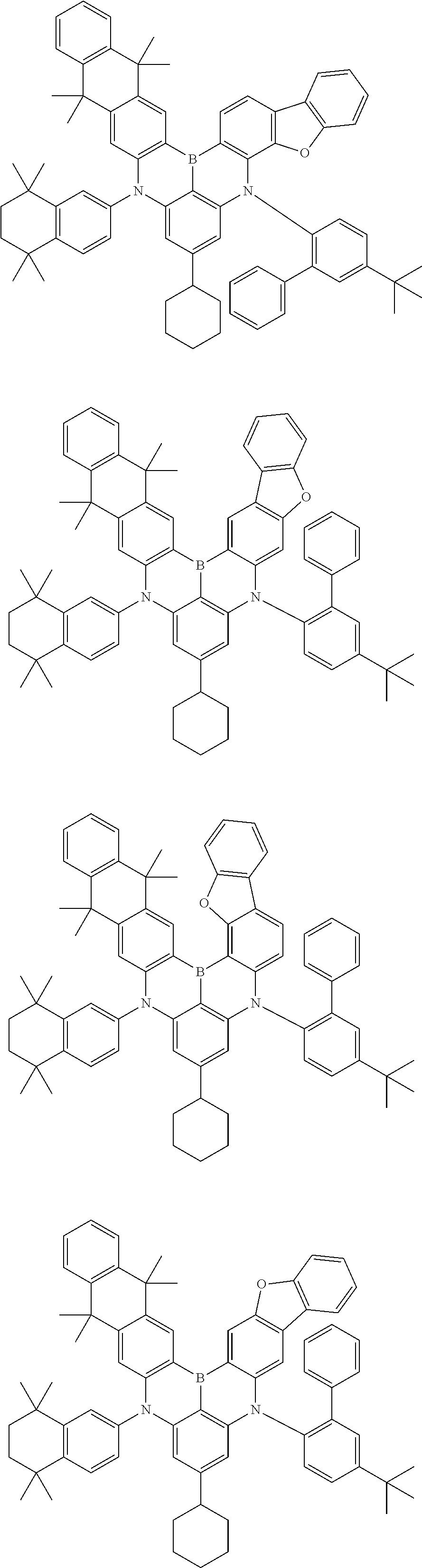

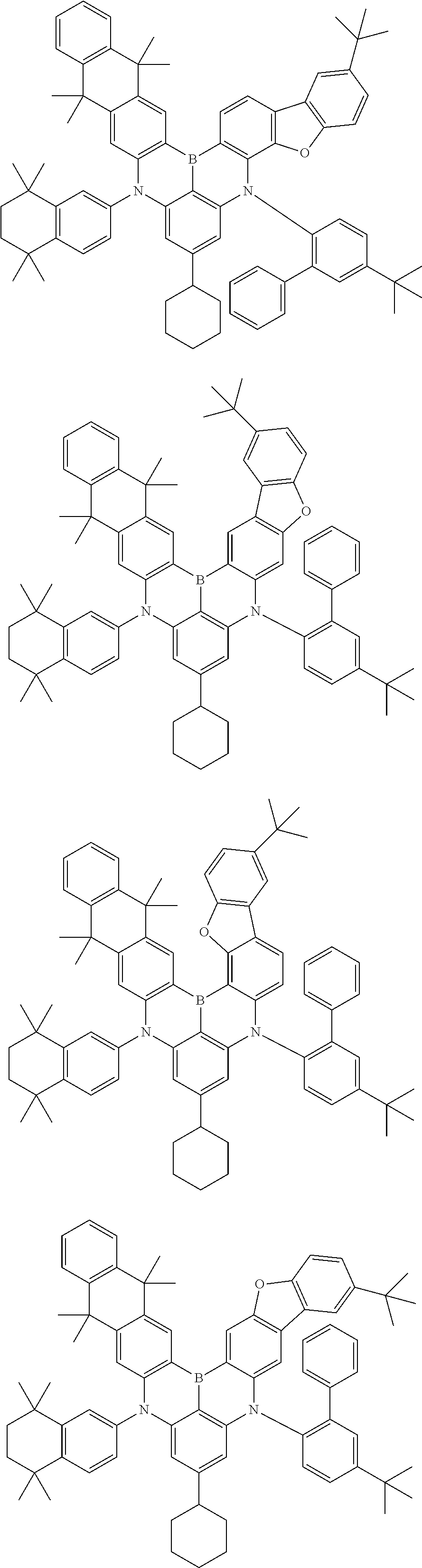

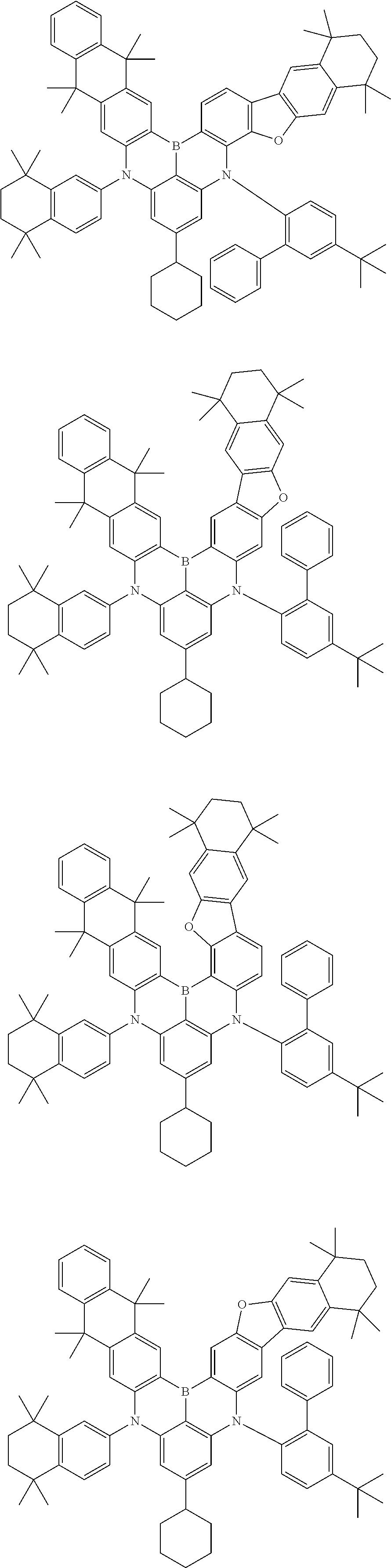

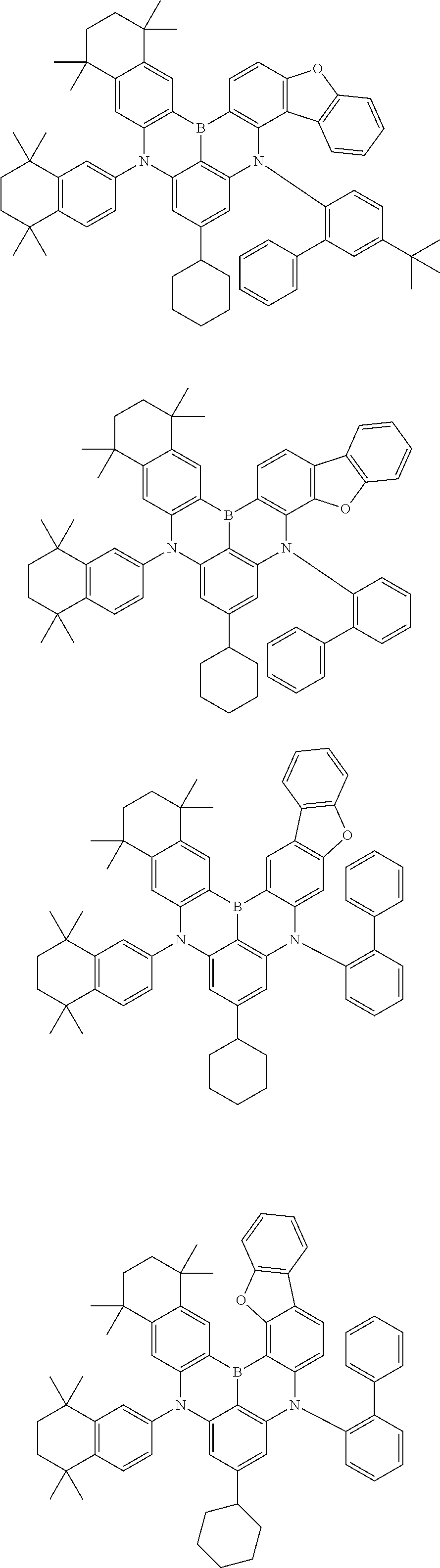 [SMILES: CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4oc5ccccc5c4c32)c(-c2ccccc2)c1 ; CC1(C)CCC(C)(C)c2cc(N3c4cc5c(cc4B4c6ccc7c(oc8ccccc87)c6N(c6ccccc6-c6ccccc6)c6cc(C7CCCCC7)cc3c64)C(C)(C)CCC5(C)C)ccc21 ; CC1(C)CCC(C)(C)c2cc(N3c4cc5c(cc4B4c6cc7c(cc6N(c6ccccc6-c6ccccc6)c6cc(C8CCCCC8)cc3c64)oc3ccccc37)C(C)(C)CCC5(C)C)ccc21 ; CC1(C)CCC(C)(C)c2cc(N3c4cc5c(cc4B4c6c3cc(C3CCCCC3)cc6N(c3ccccc3-c3ccccc3)c3ccc6c(oc7ccccc76)c34)C(C)(C)CCC5(C)C)ccc21]

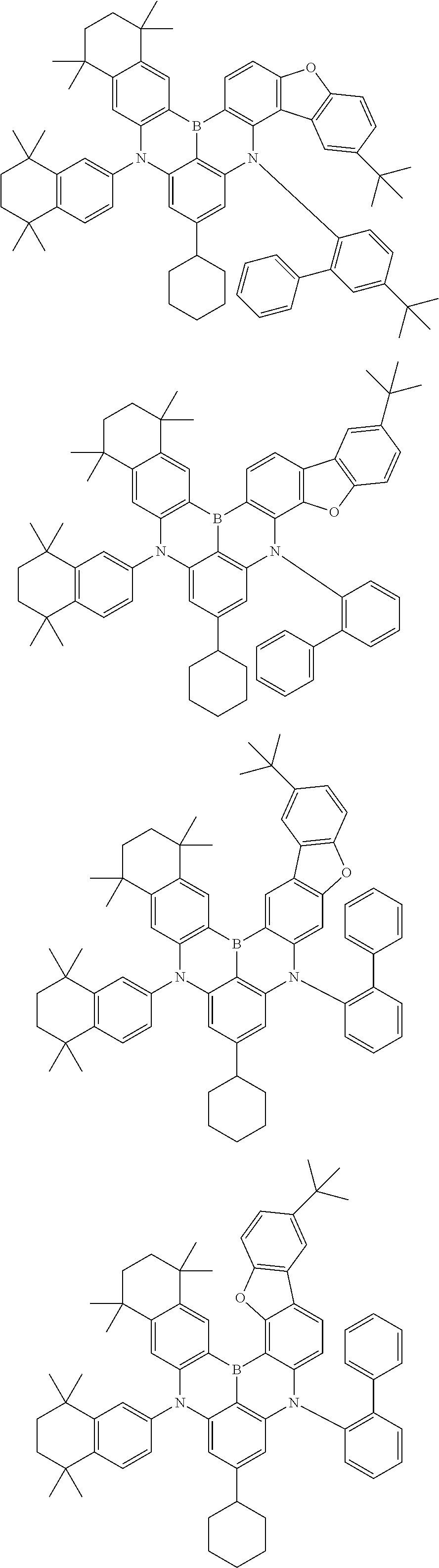

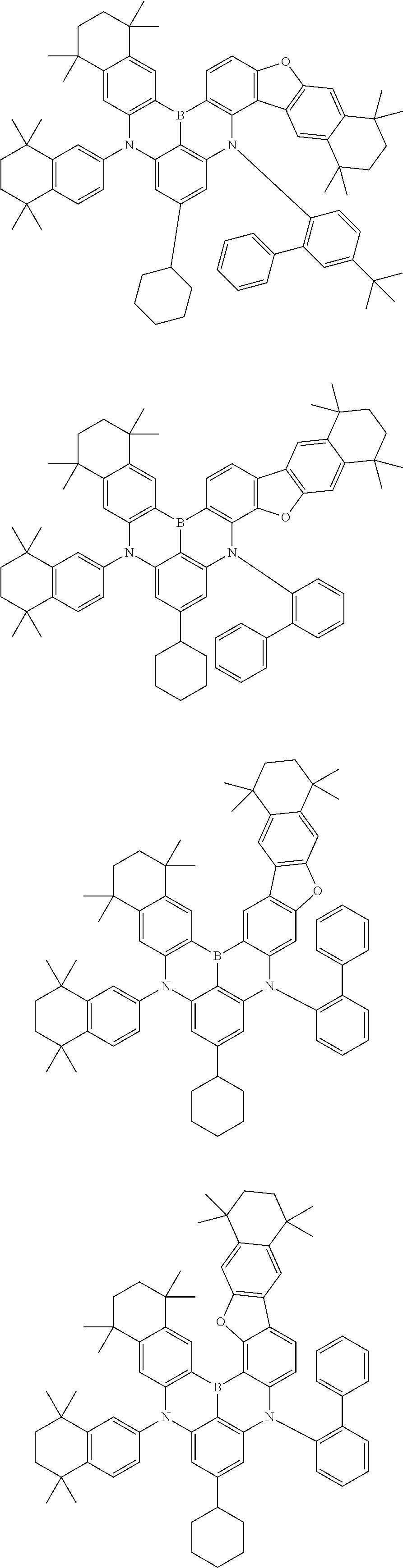

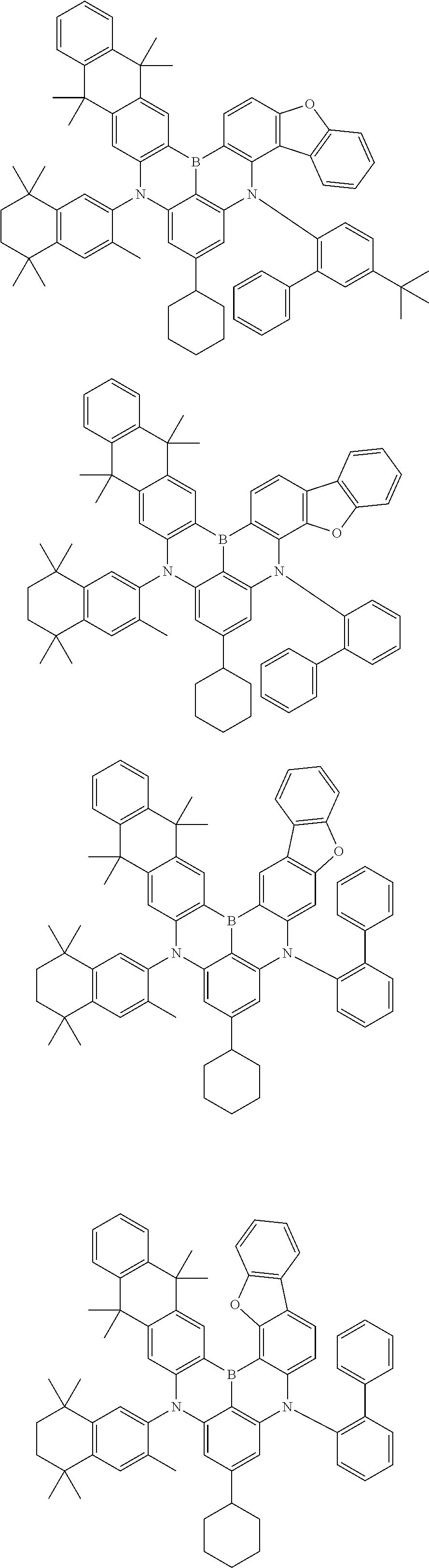

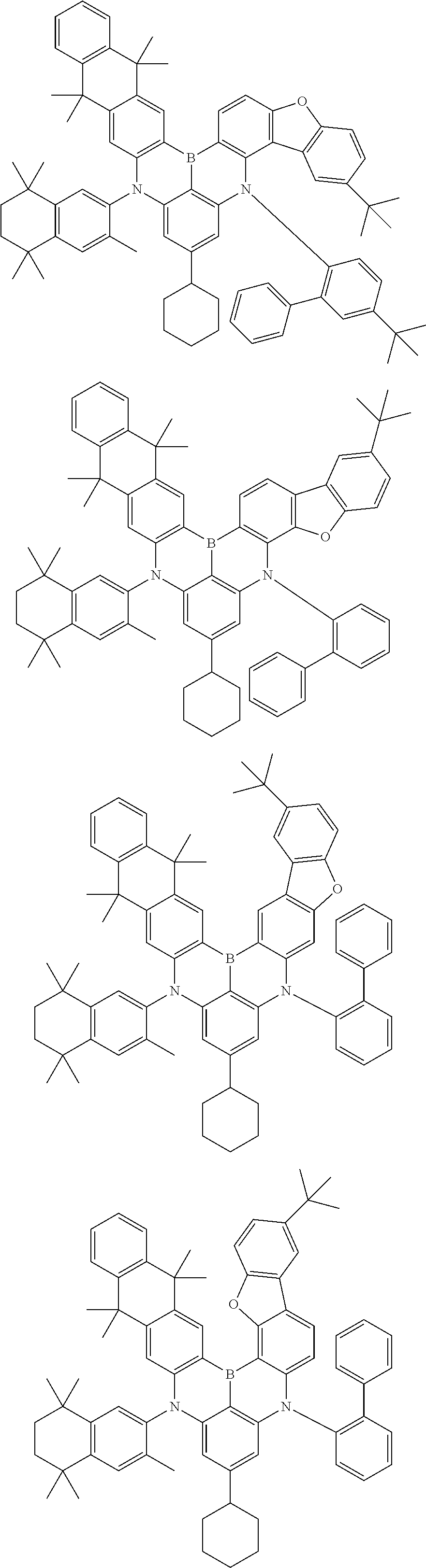

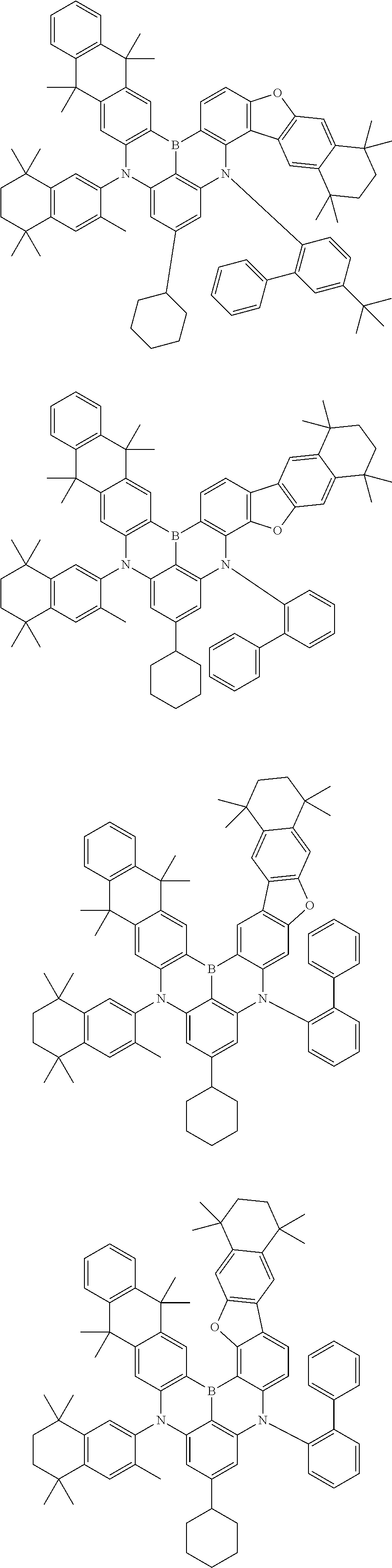

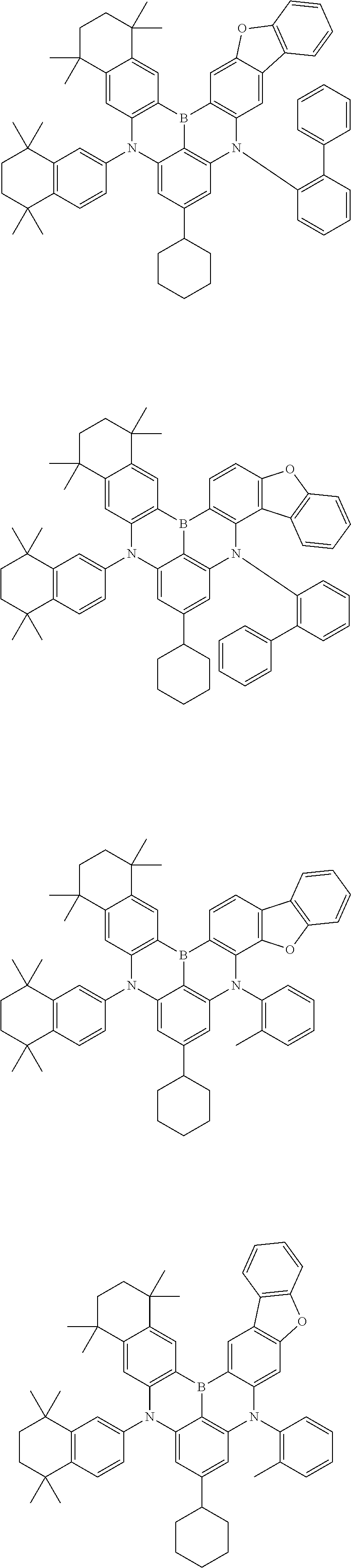 [SMILES: CC1(C)CCC(C)(C)c2cc(N3c4cc5c(cc4B4c6cc7oc8ccccc8c7cc6N(c6ccccc6-c6ccccc6)c6cc(C7CCCCC7)cc3c64)C(C)(C)CCC5(C)C)ccc21 ; CC1(C)CCC(C)(C)c2cc(N3c4cc5c(cc4B4c6ccc7oc8ccccc8c7c6N(c6ccccc6-c6ccccc6)c6cc(C7CCCCC7)cc3c64)C(C)(C)CCC5(C)C)ccc21 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(oc4ccccc43)c21 ; Cc1ccccc1N1c2cc3oc4ccccc4c3cc2B2c3cc4c(cc3N(c3ccc5c(c3)C(C)(C)CCC5(C)C)c3cc(C5CCCCC5)cc1c32)C(C)(C)CCC4(C)C]

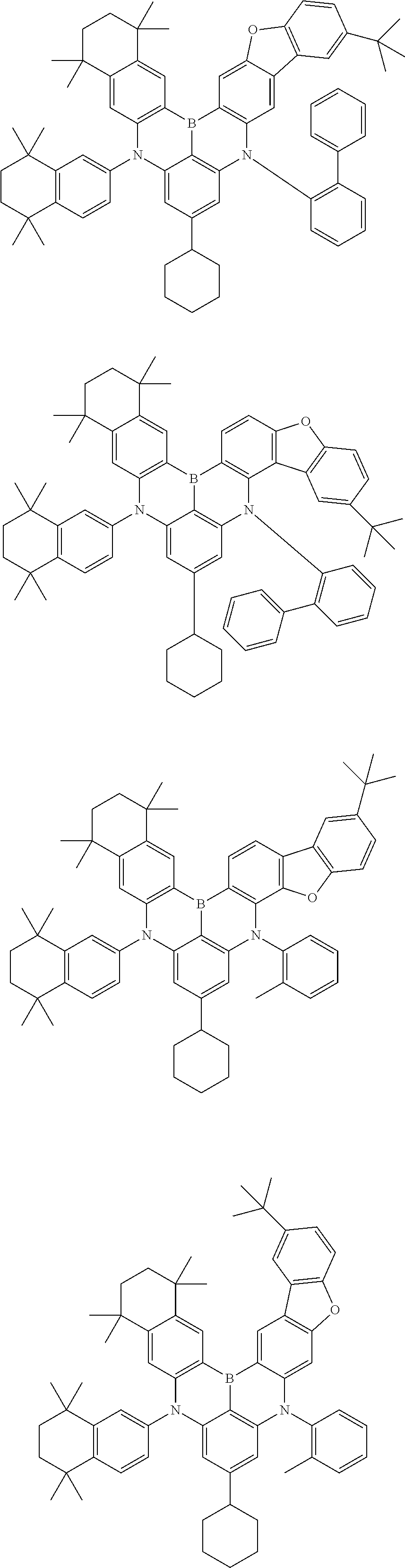 [SMILES: CC(C)(C)c1ccc2oc3cc4c(cc3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; CC(C)(C)c1ccc2oc3ccc4c(c3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)CCC5(C)C)c3cc(C5CCCCC5)cc1c32)C(C)(C)CCC4(C)C]

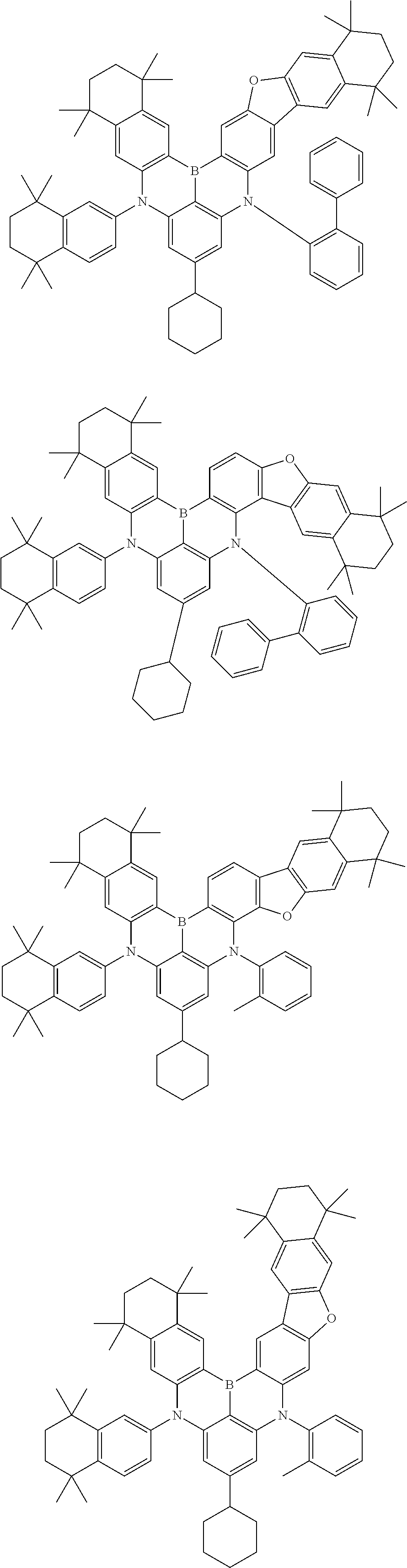

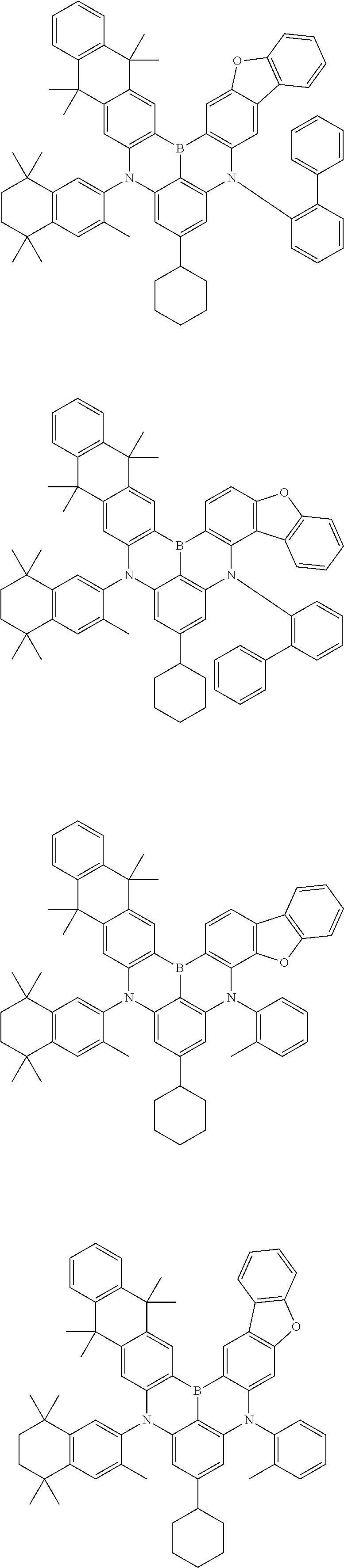 [SMILES: Cc1cc2c(cc1N1c3cc4c(cc3B3c5cc6oc7ccccc7c6cc5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5C)c5cc(C6CCCCC6)cc1c53)C(C)(C)c1ccccc1C4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(C5CCCCC5)cc1c32)C(C)(C)c1ccccc1C4(C)C]

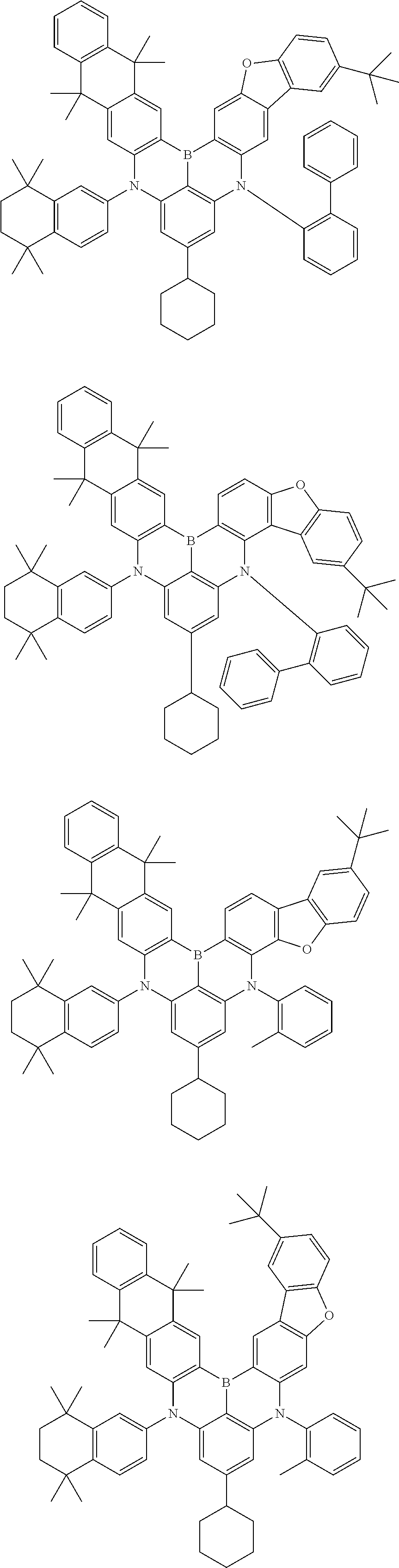

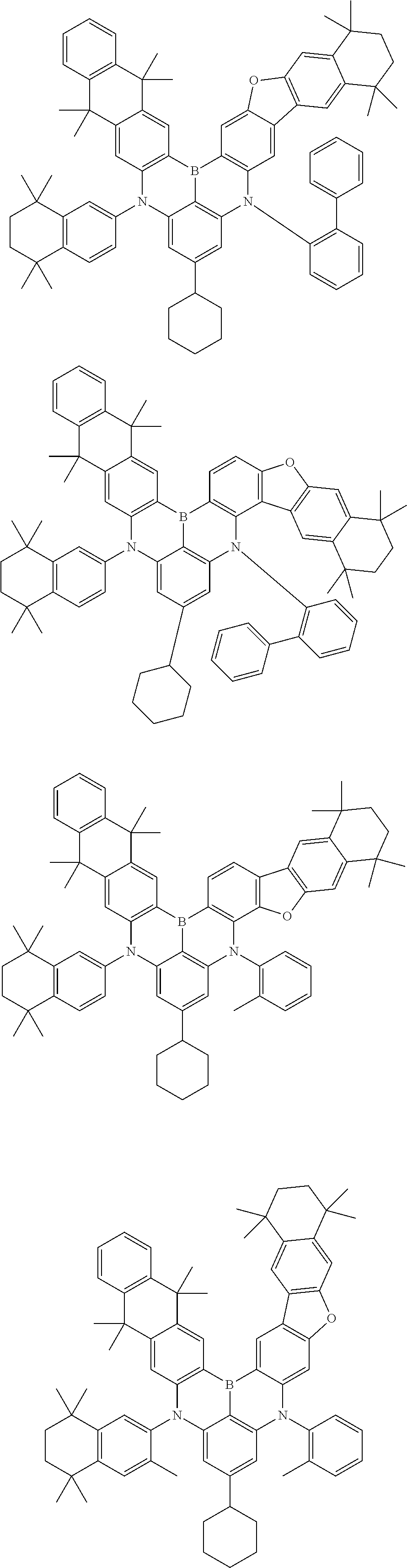

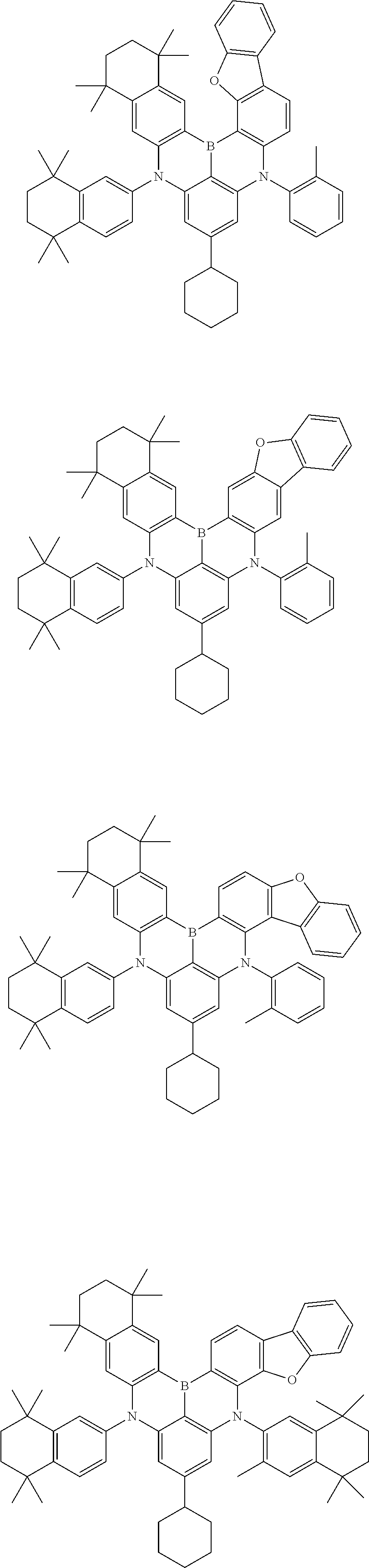 [SMILES: Cc1ccccc1N1c2cc(C3CCCCC3)cc3c2B(c2cc4c(cc2N3c2ccc3c(c2)C(C)(C)CCC3(C)C)C(C)(C)CCC4(C)C)c2c1ccc1c2oc2ccccc21 ; Cc1ccccc1N1c2cc3c(cc2B2c4cc5c(cc4N(c4ccc6c(c4)C(C)(C)CCC6(C)C)c4cc(C6CCCCC6)cc1c42)C(C)(C)CCC5(C)C)oc1ccccc13 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3oc4ccccc4c3c21 ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(oc5ccccc54)c31)C(C)(C)CCC2(C)C]

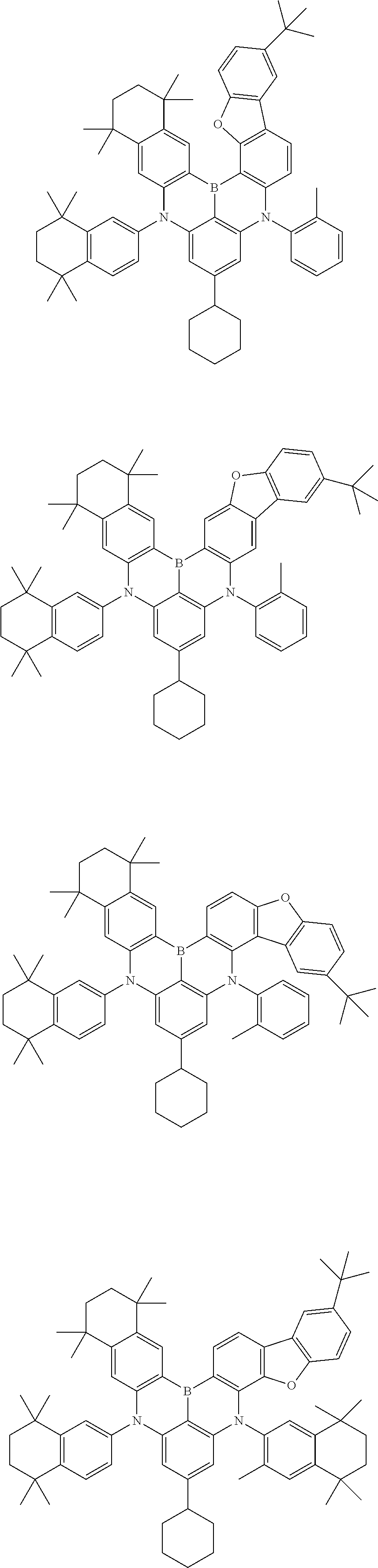 [SMILES: Cc1ccccc1N1c2cc(C3CCCCC3)cc3c2B(c2cc4c(cc2N3c2ccc3c(c2)C(C)(C)CCC3(C)C)C(C)(C)CCC4(C)C)c2c1ccc1c2oc2ccc(C(C)(C)C)cc21 ; Cc1ccccc1N1c2cc3c(cc2B2c4cc5c(cc4N(c4ccc6c(c4)C(C)(C)CCC6(C)C)c4cc(C6CCCCC6)cc1c42)C(C)(C)CCC5(C)C)oc1ccc(C(C)(C)C)cc13 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21 ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C]

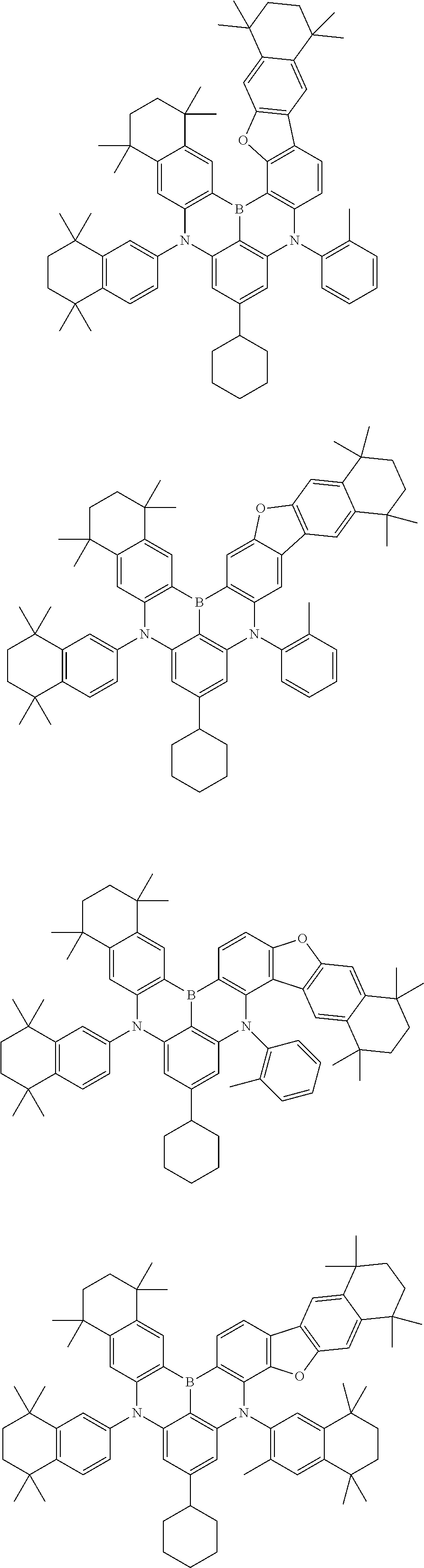

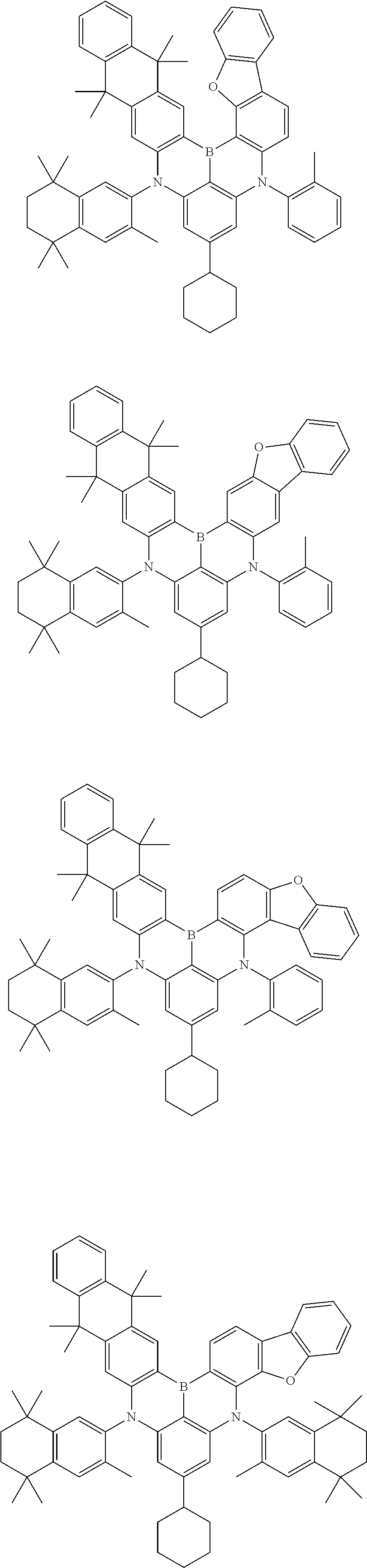 [SMILES: Cc1cc2c(cc1N1c3cc4c(cc3B3c5c1cc(C1CCCCC1)cc5N(c1ccccc1C)c1ccc5c(oc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)oc1ccccc13 ; Cc1cc2c(cc1N1c3cc4c(cc3B3c5ccc6oc7ccccc7c6c5N(c5ccccc5C)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(C6CCCCC6)cc1c53)C(C)(C)c1ccccc1C4(C)C)C(C)(C)CCC2(C)C]

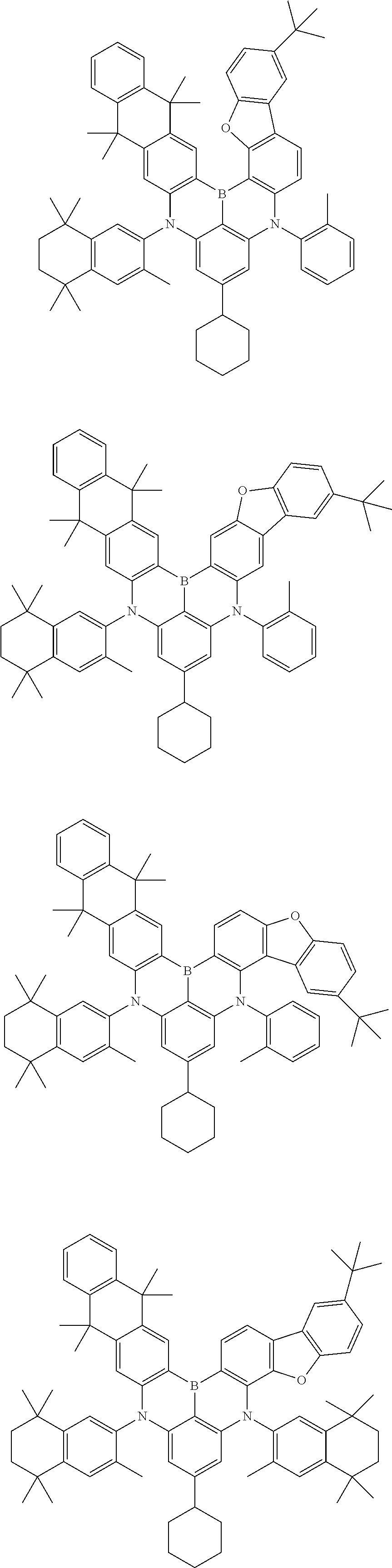

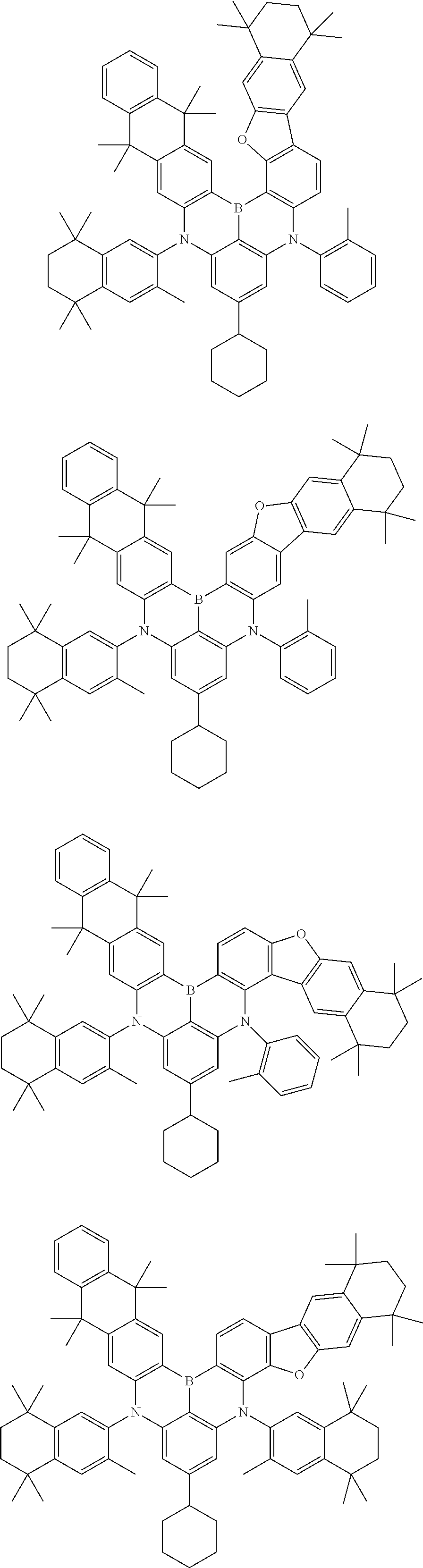

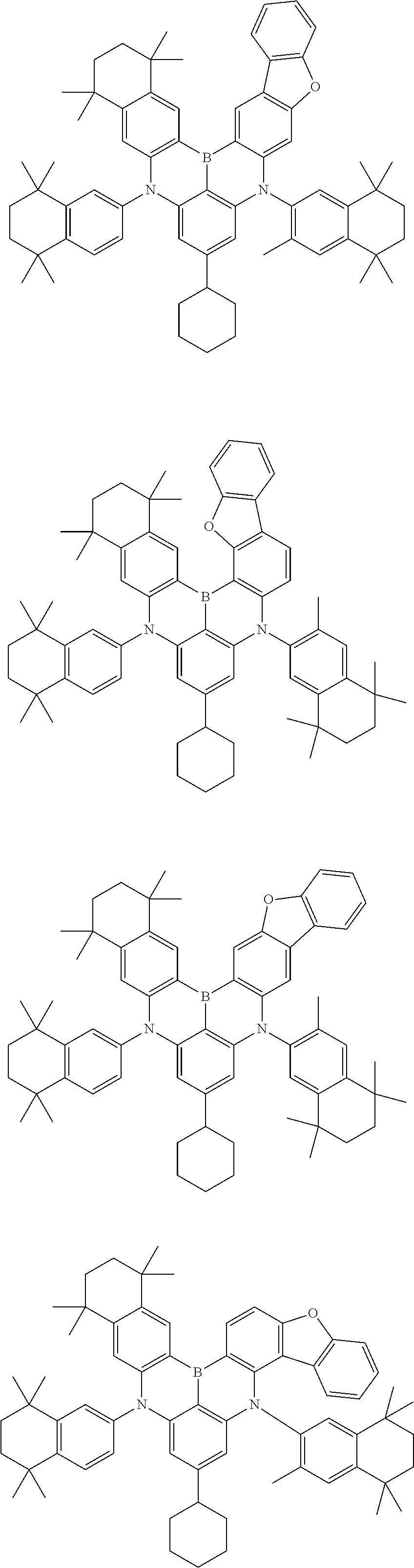

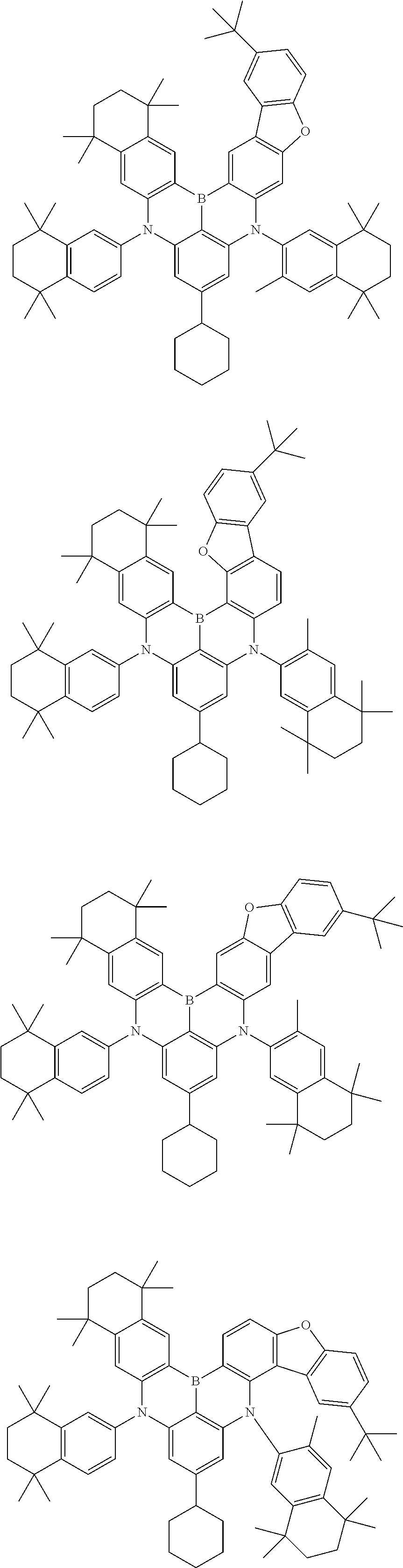

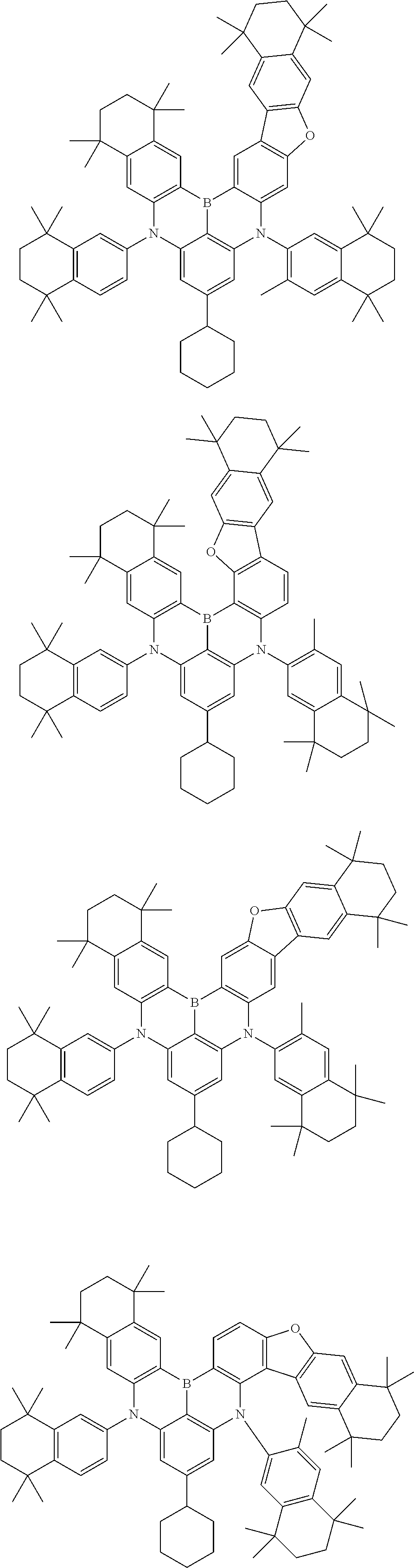

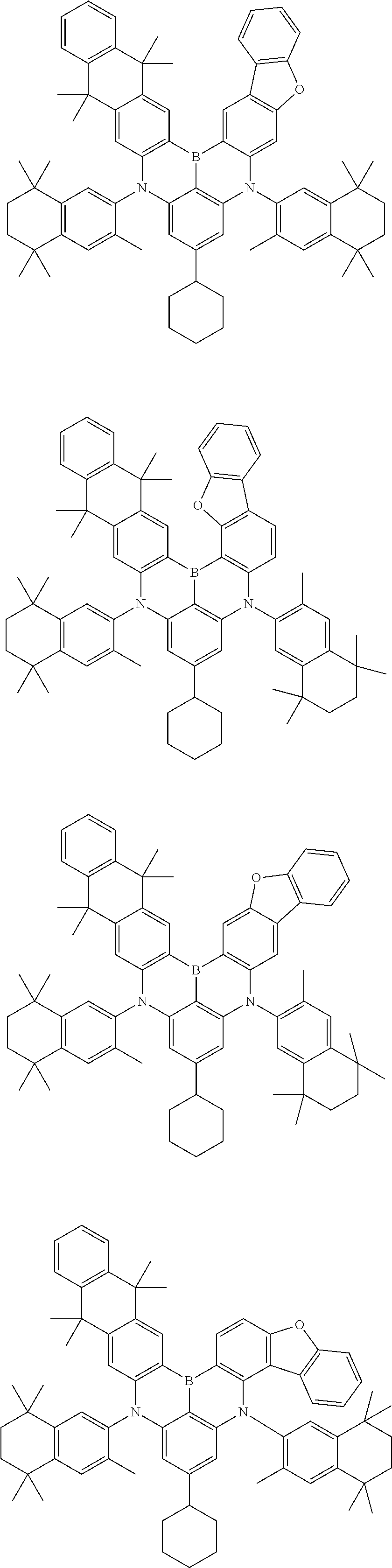

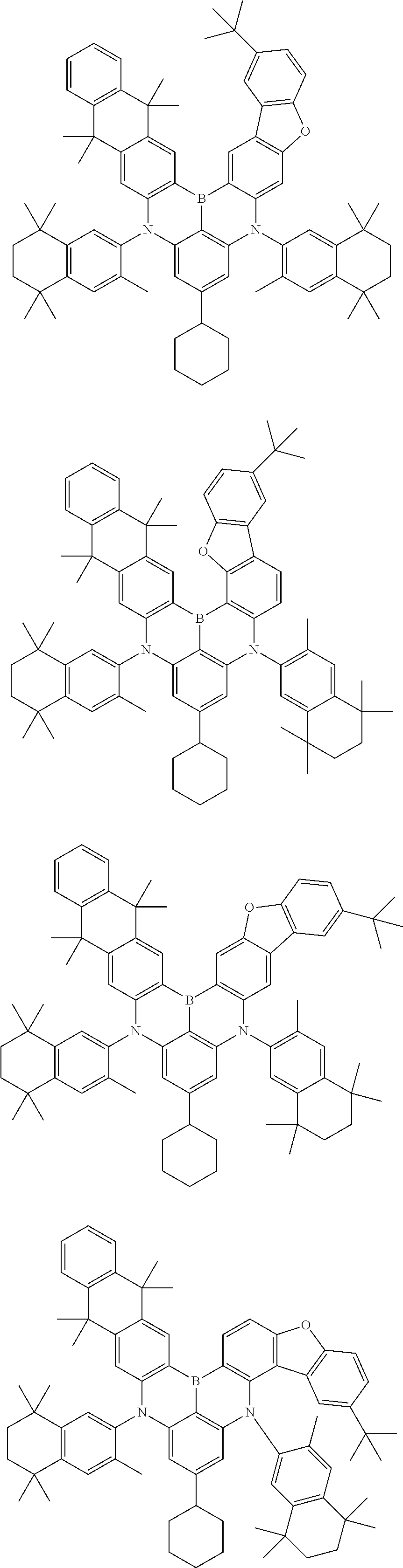

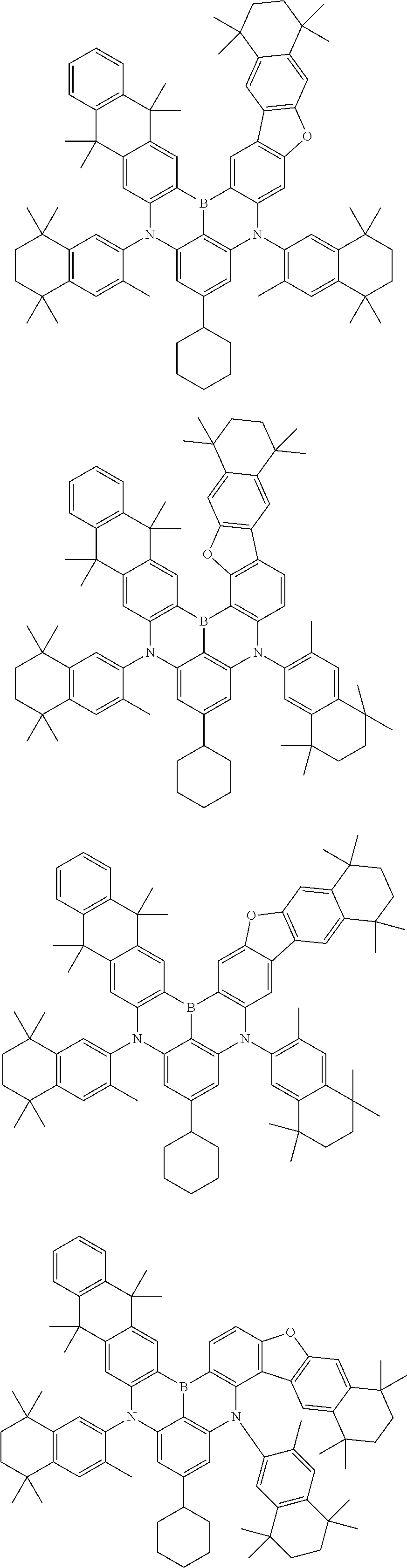

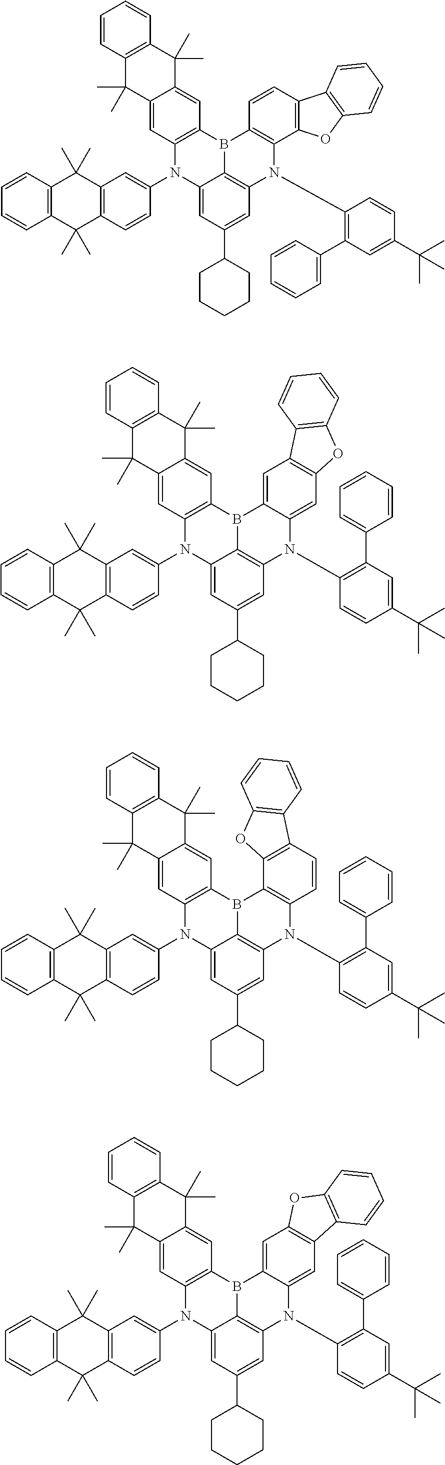

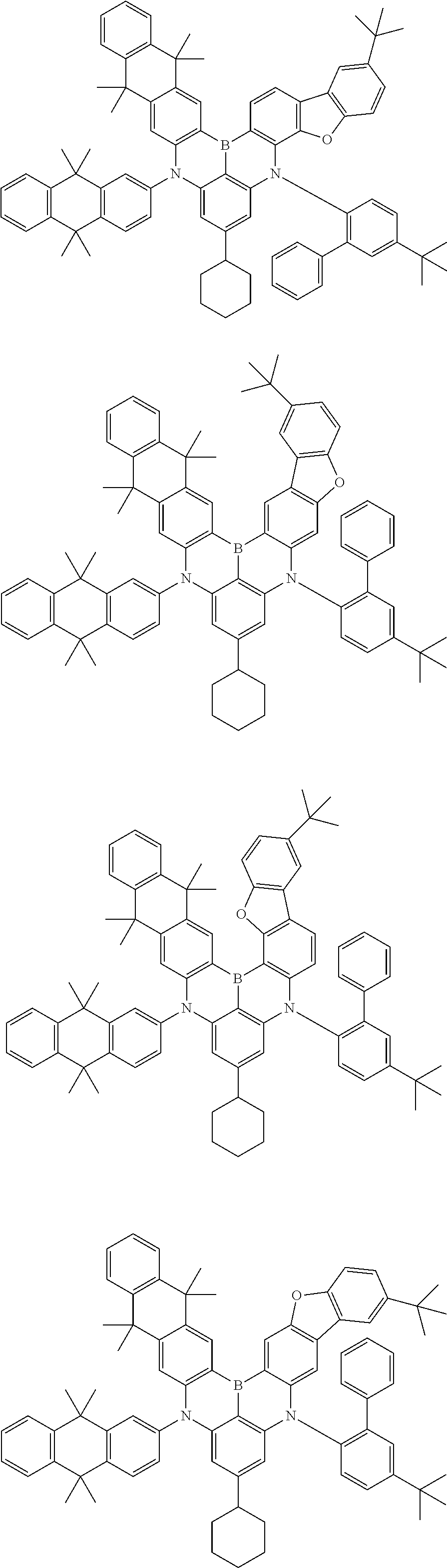

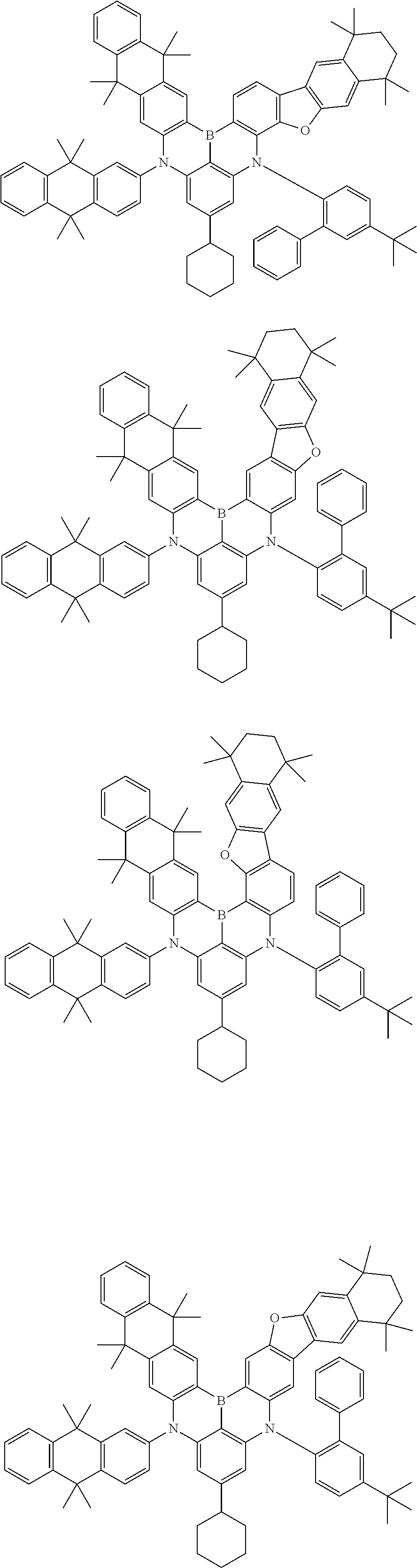

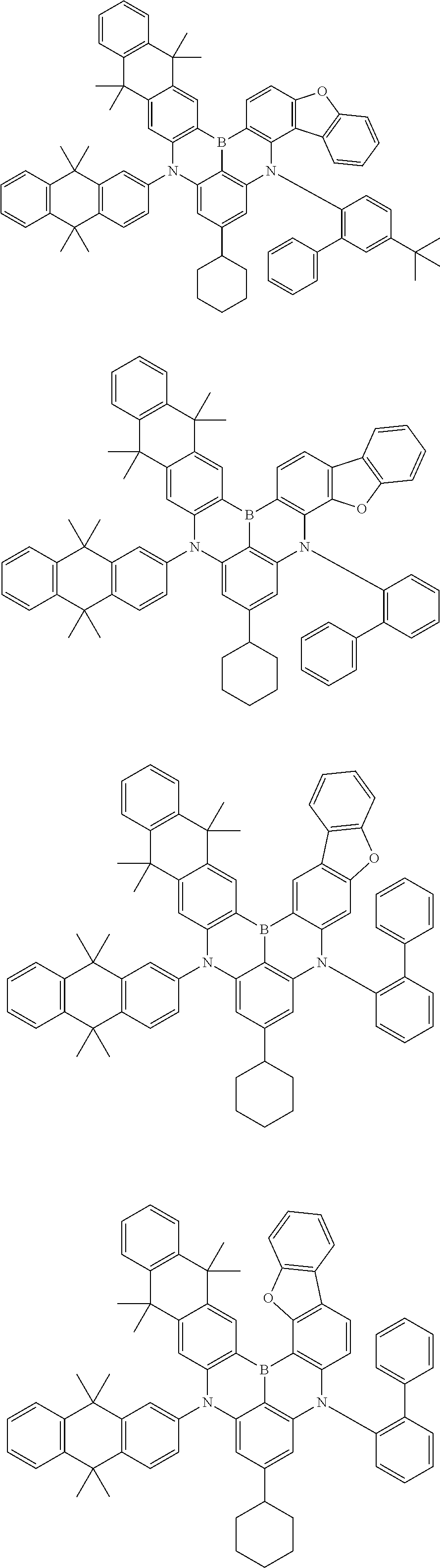

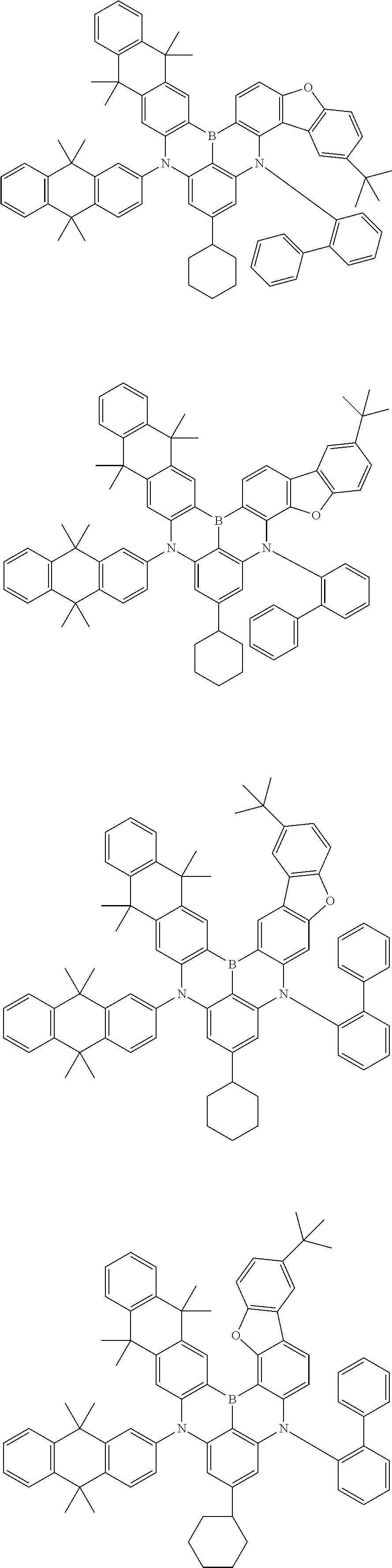

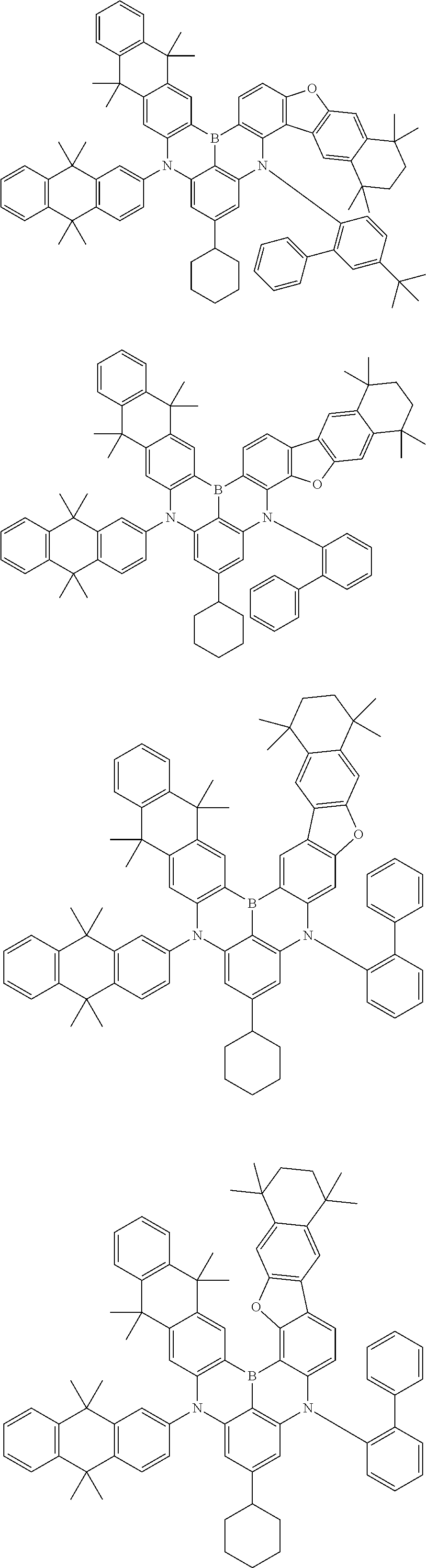

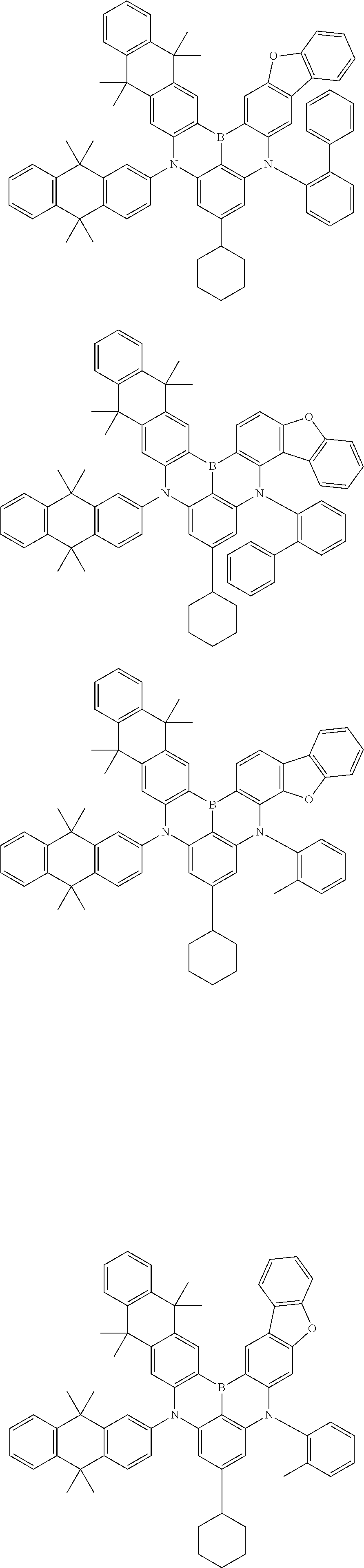

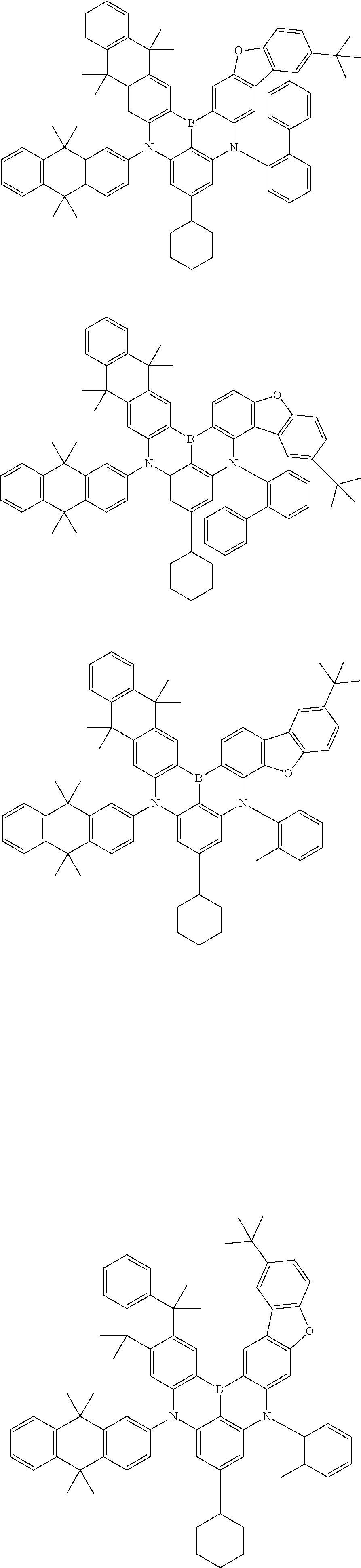

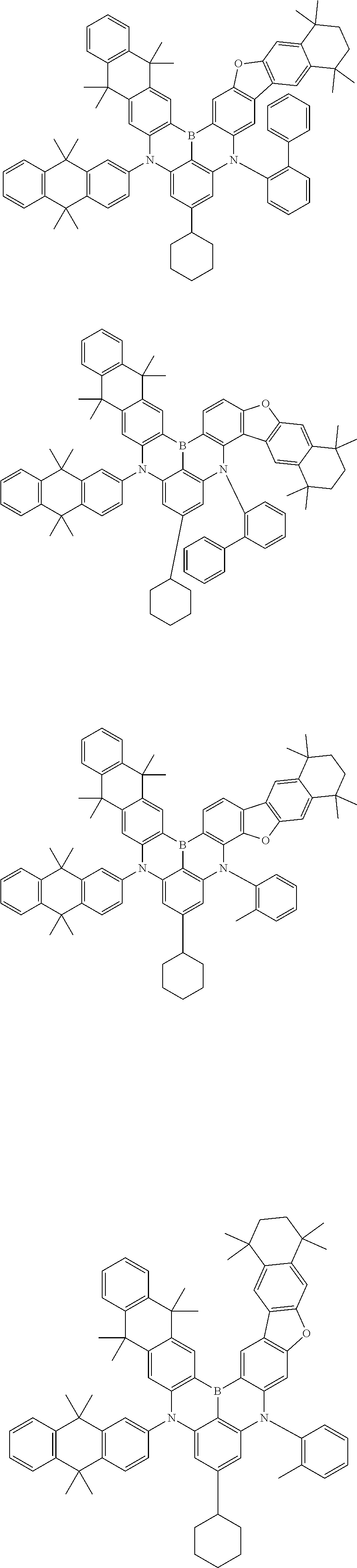

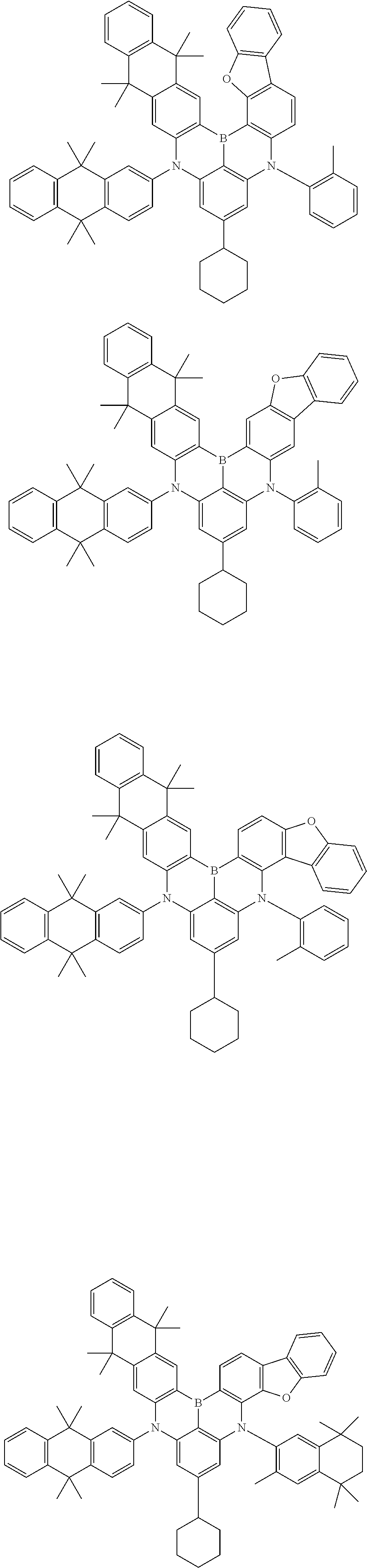

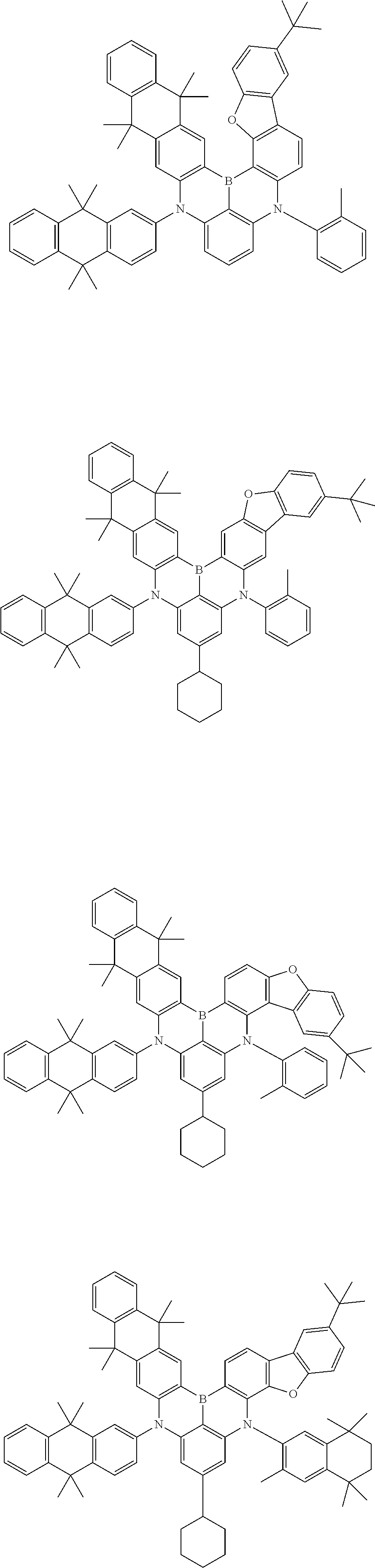

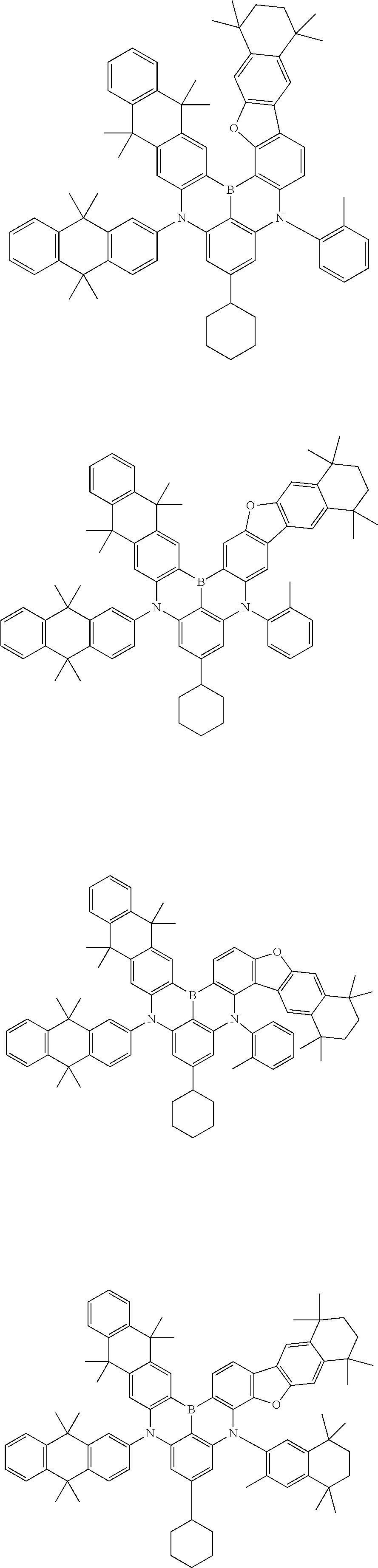

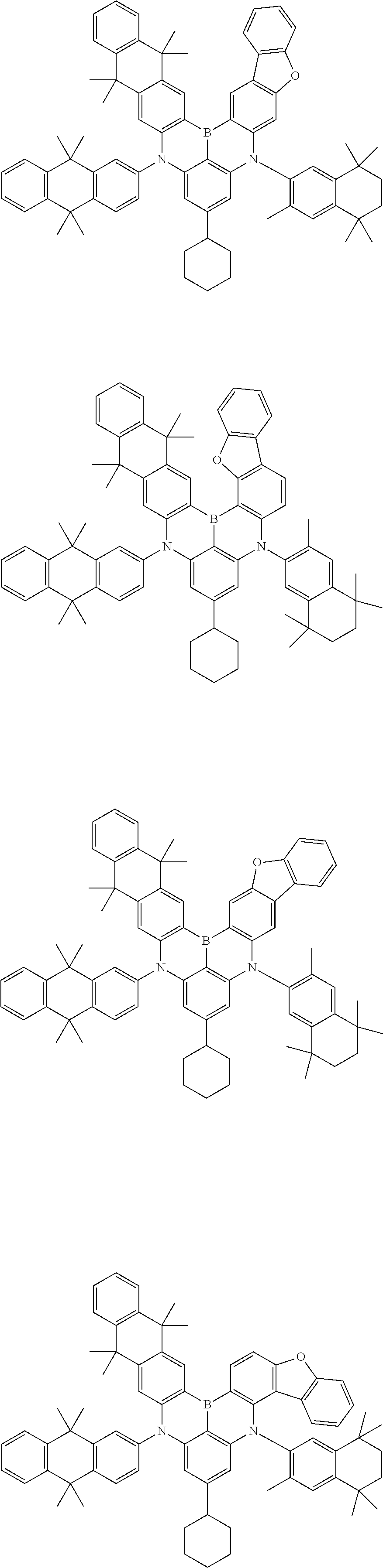

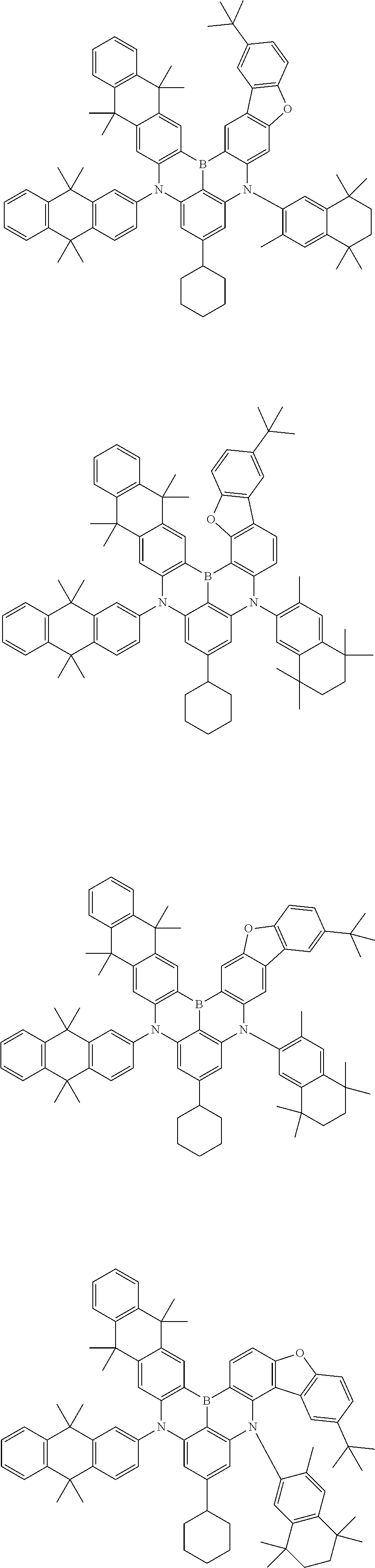

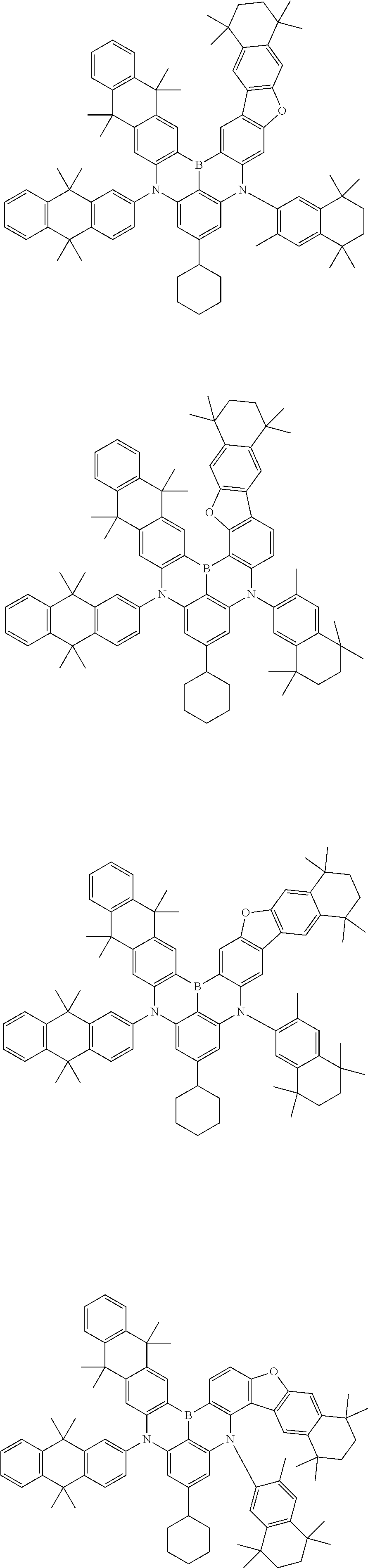

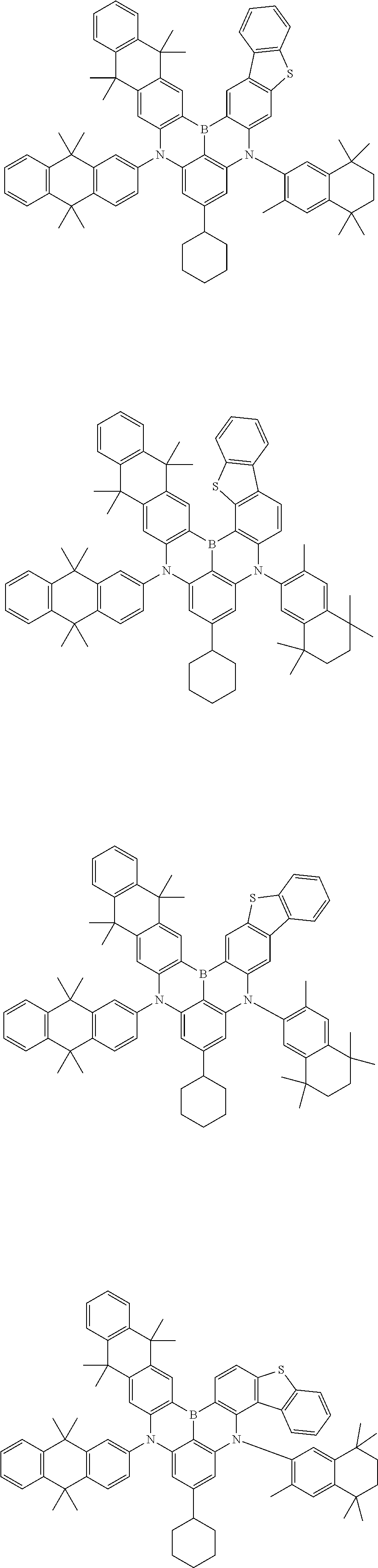

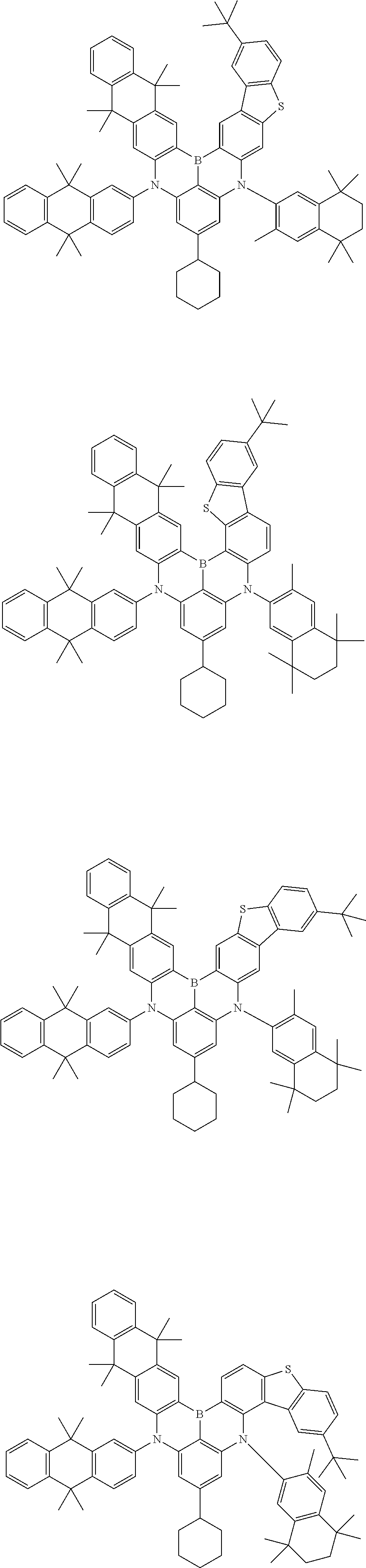

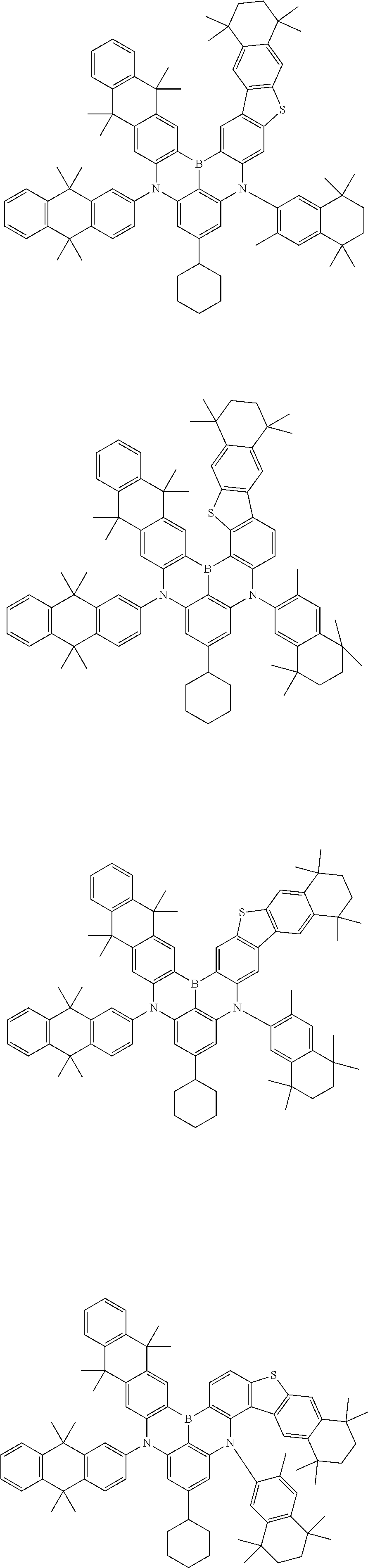

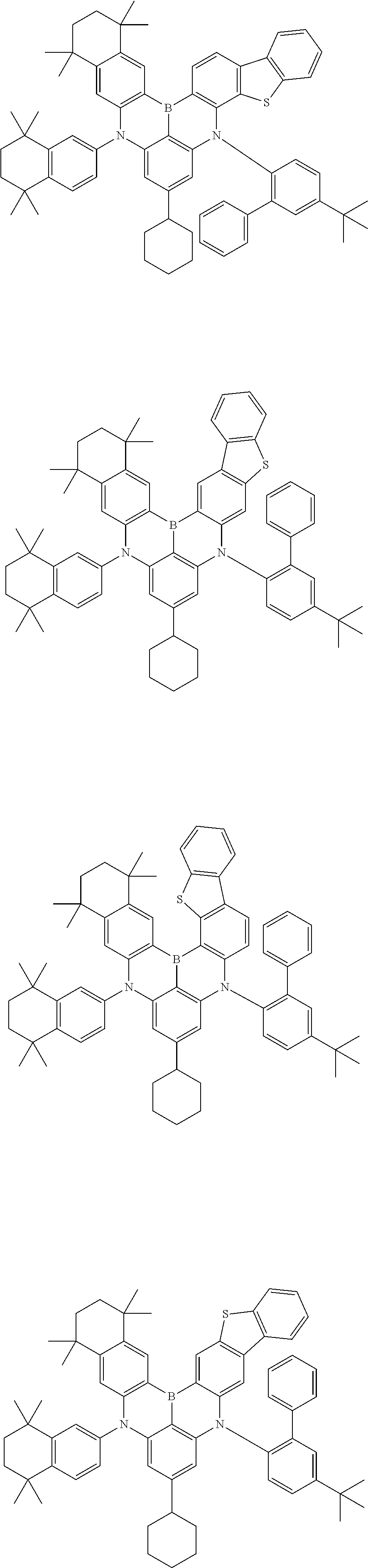

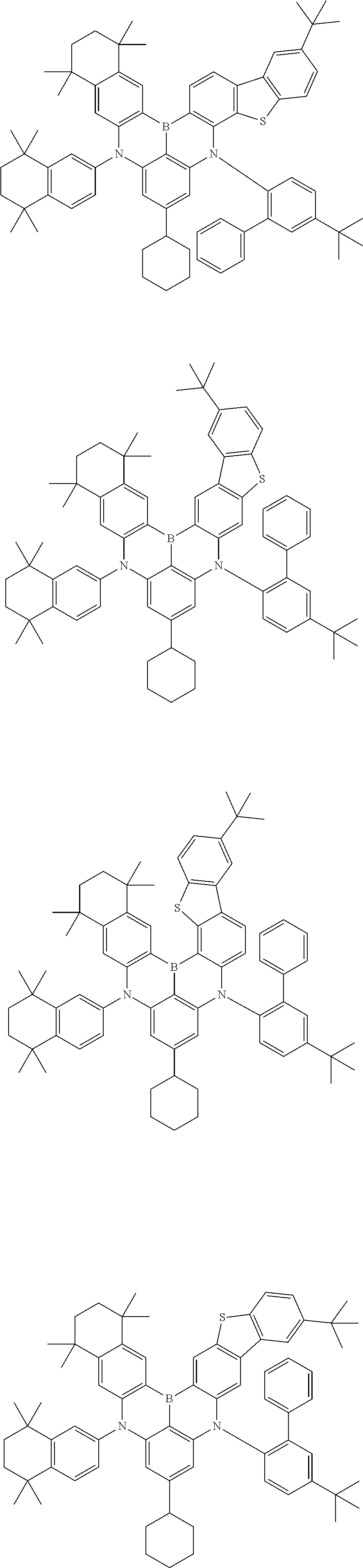

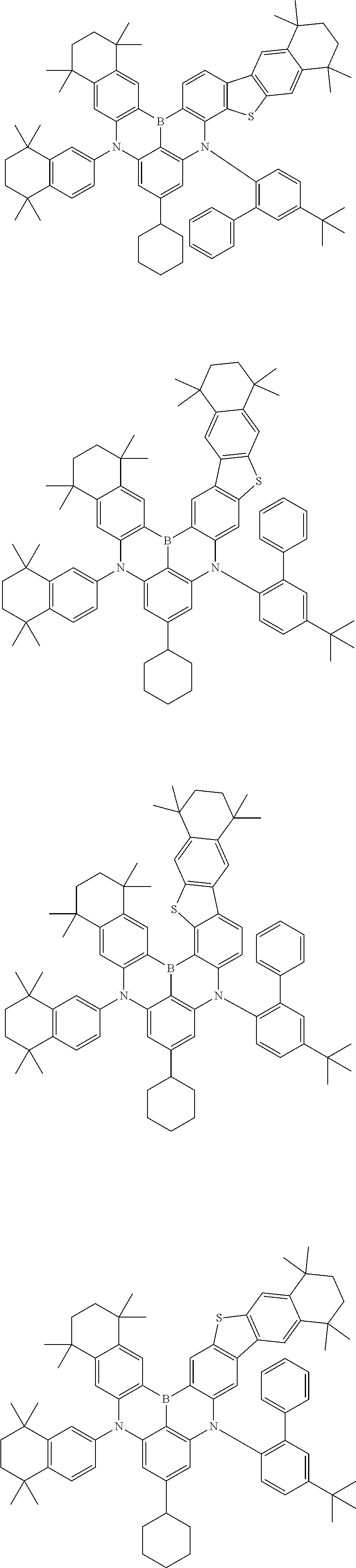

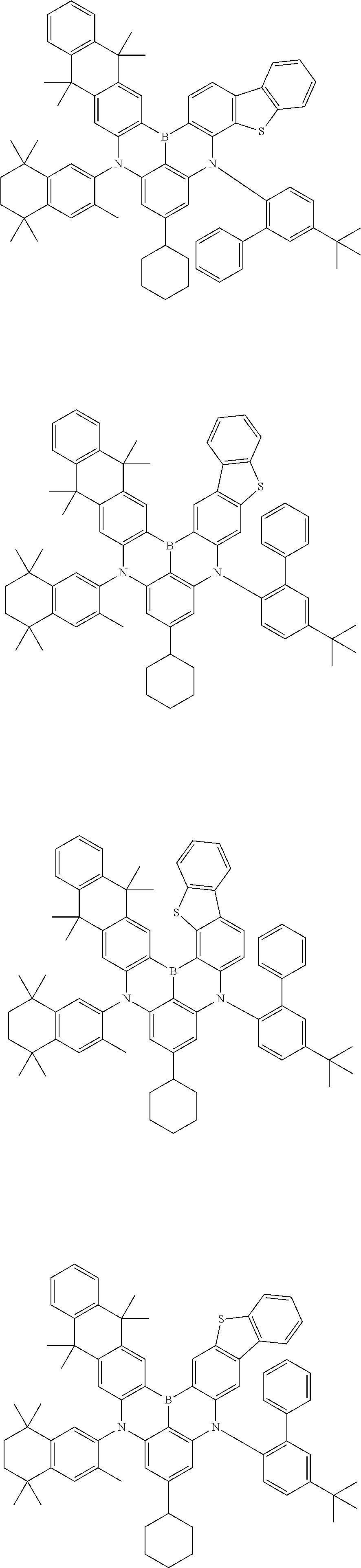

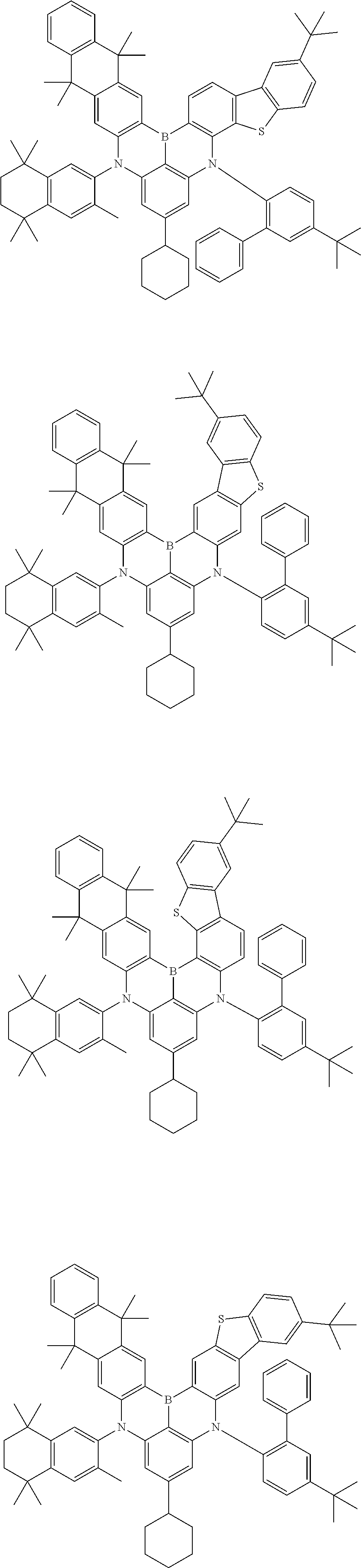

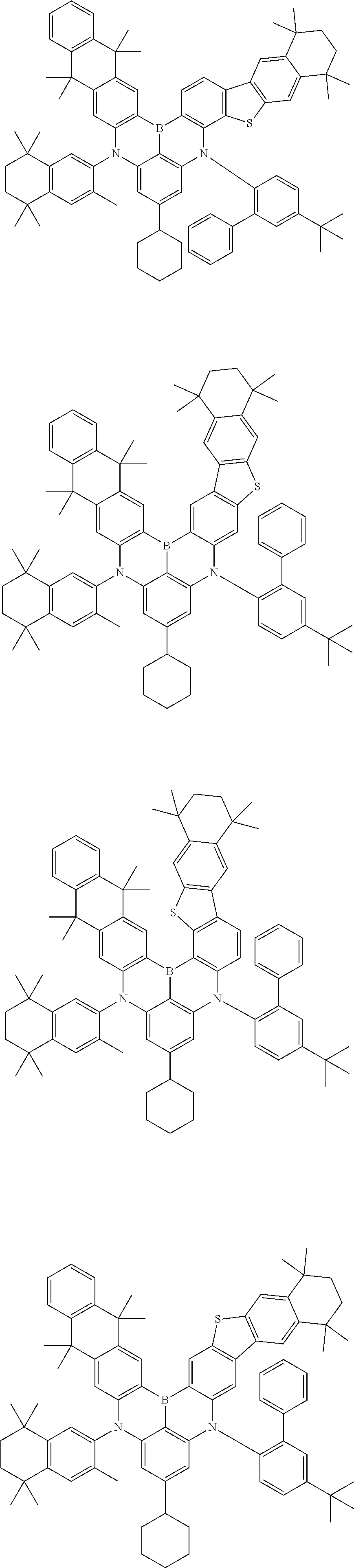

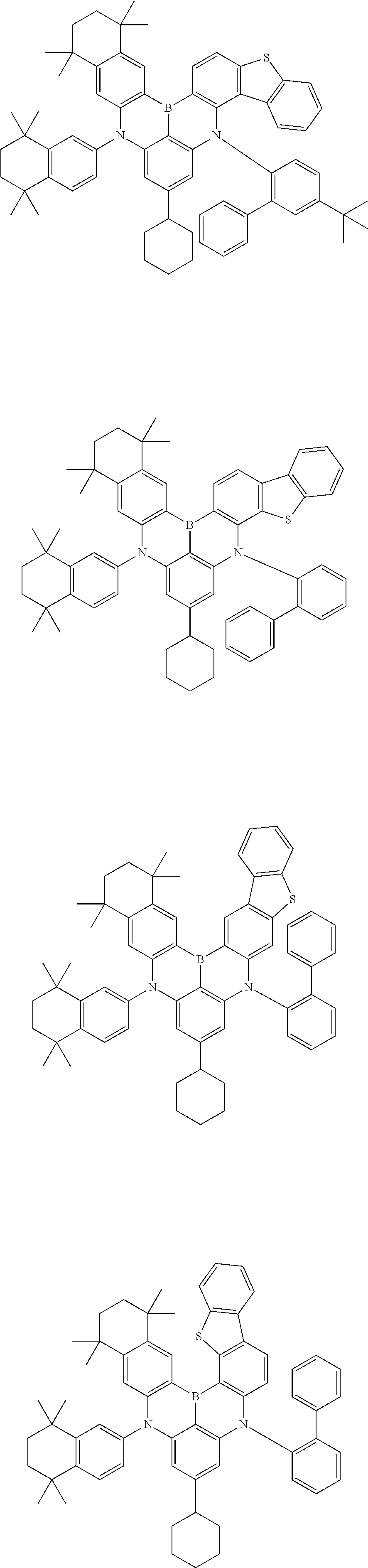 [SMILES: CC(C)(C)c1ccc(N2c3cc(C4CCCCC4)cc4c3B(c3cc5c(cc3N4c3ccc4c(c3)C(C)(C)CCC4(C)C)C(C)(C)CCC5(C)C)c3ccc4sc5ccccc5c4c32)c(-c2ccccc2)c1 ; CC1(C)CCC(C)(C)c2cc(N3c4cc5c(cc4B4c6ccc7c(sc8ccccc87)c6N(c6ccccc6-c6ccccc6)c6cc(C7CCCCC7)cc3c64)C(C)(C)CCC5(C)C)ccc21 ; CC1(C)CCC(C)(C)c2cc(N3c4cc5c(cc4B4c6cc7c(cc6N(c6ccccc6-c6ccccc6)c6cc(C8CCCCC8)cc3c64)sc3ccccc37)C(C)(C)CCC5(C)C)ccc21 ; CC1(C)CCC(C)(C)c2cc(N3c4cc5c(cc4B4c6c3cc(C3CCCCC3)cc6N(c3ccccc3-c3ccccc3)c3ccc6c(sc7ccccc76)c34)C(C)(C)CCC5(C)C)ccc21]

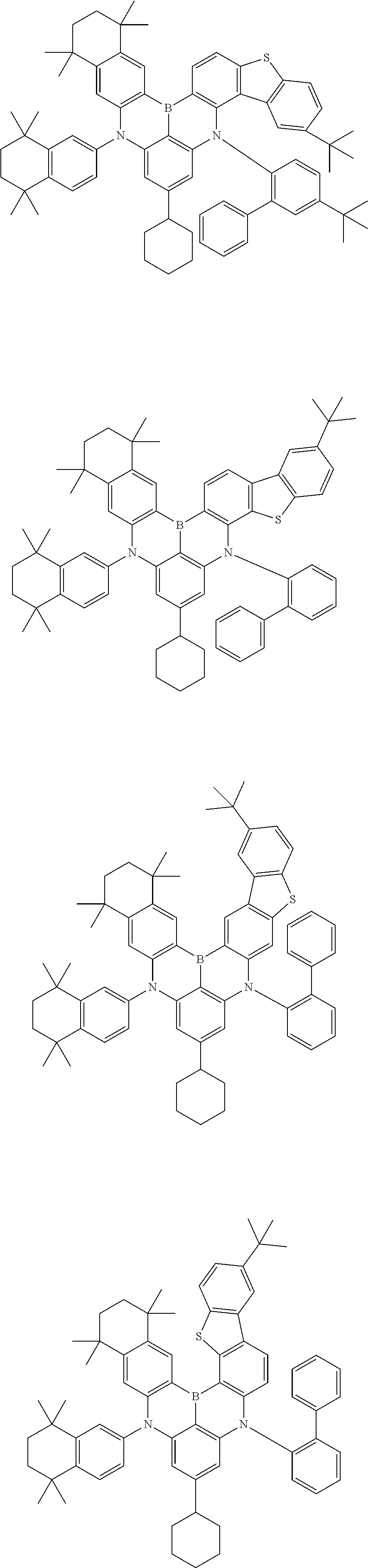

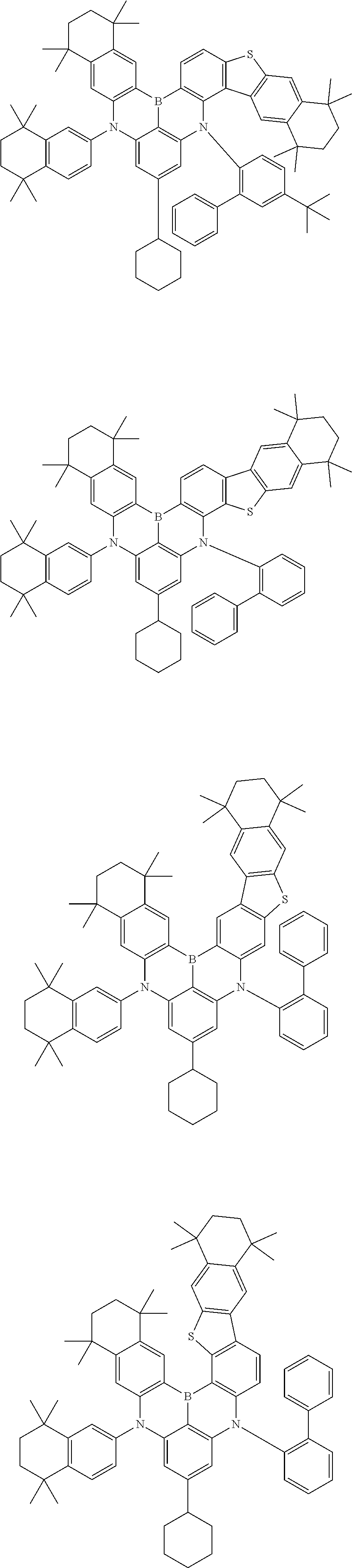

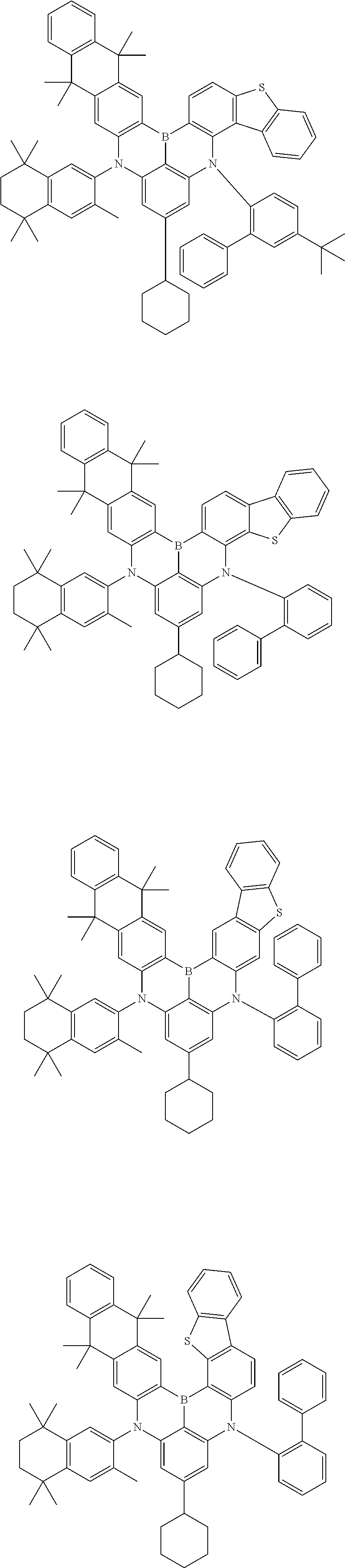

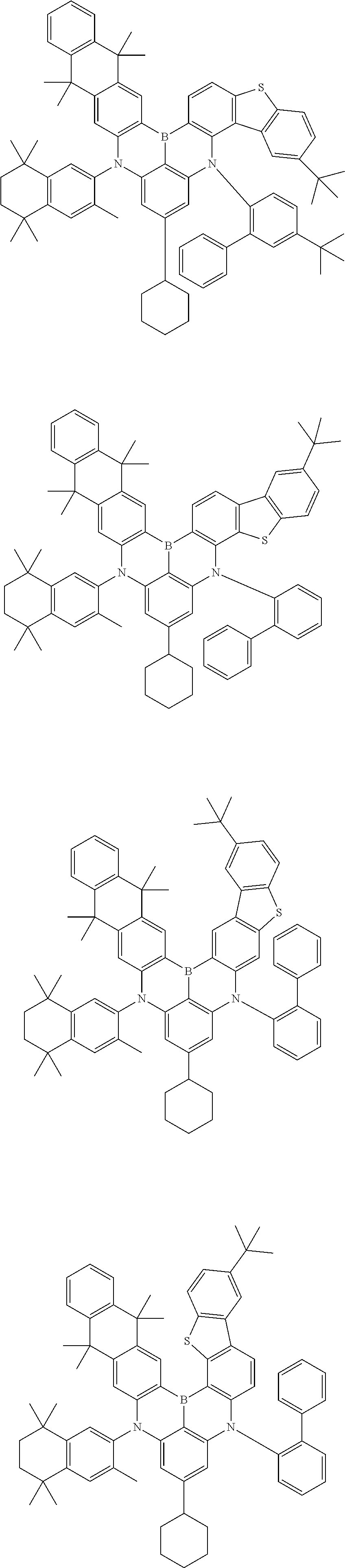

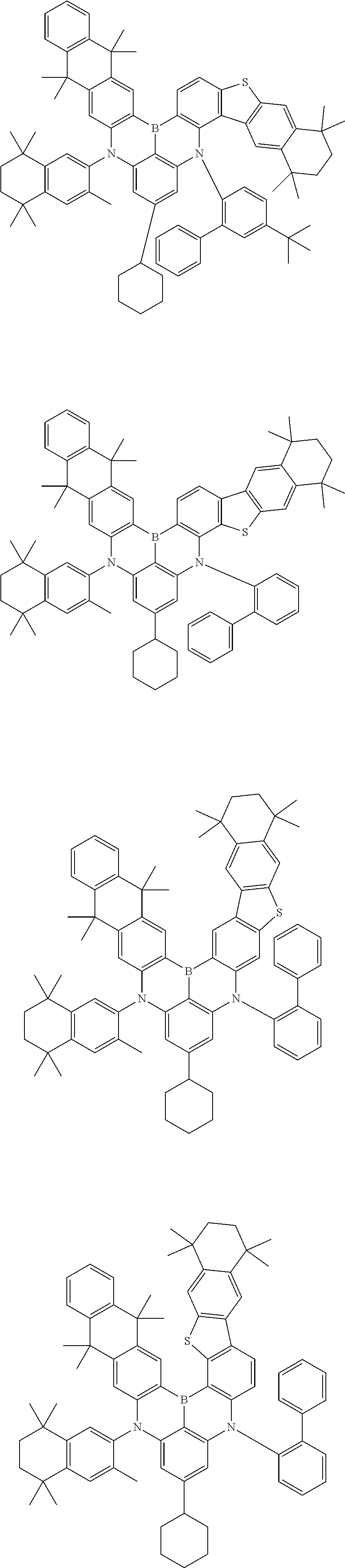

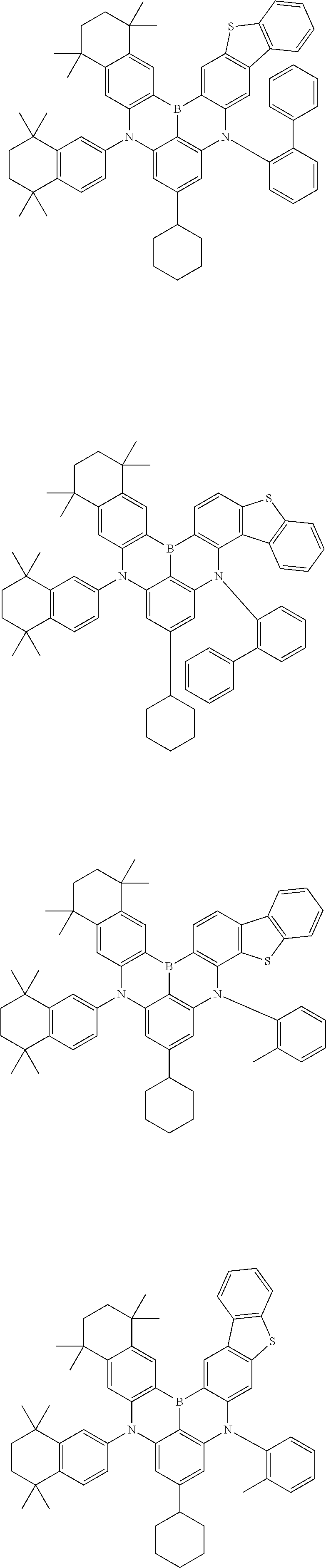 [SMILES: CC1(C)CCC(C)(C)c2cc(N3c4cc5c(cc4B4c6cc7sc8ccccc8c7cc6N(c6ccccc6-c6ccccc6)c6cc(C7CCCCC7)cc3c64)C(C)(C)CCC5(C)C)ccc21 ; CC1(C)CCC(C)(C)c2cc(N3c4cc5c(cc4B4c6ccc7sc8ccccc8c7c6N(c6ccccc6-c6ccccc6)c6cc(C7CCCCC7)cc3c64)C(C)(C)CCC5(C)C)ccc21 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(sc4ccccc43)c21 ; Cc1ccccc1N1c2cc3sc4ccccc4c3cc2B2c3cc4c(cc3N(c3ccc5c(c3)C(C)(C)CCC5(C)C)c3cc(C5CCCCC5)cc1c32)C(C)(C)CCC4(C)C]

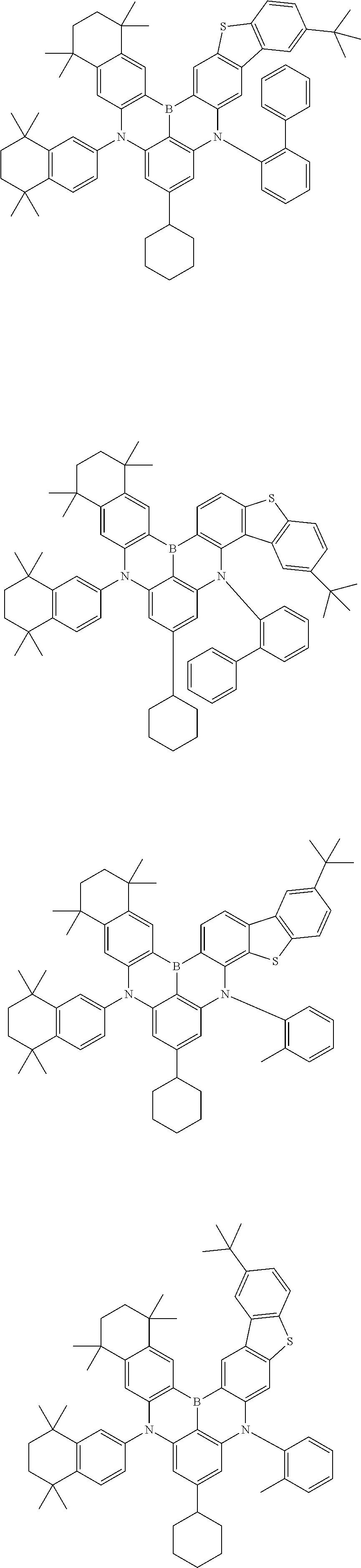 [SMILES: CC(C)(C)c1ccc2sc3cc4c(cc3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; CC(C)(C)c1ccc2sc3ccc4c(c3c2c1)N(c1ccccc1-c1ccccc1)c1cc(C2CCCCC2)cc2c1B4c1cc3c(cc1N2c1ccc2c(c1)C(C)(C)CCC2(C)C)C(C)(C)CCC3(C)C ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3c(sc4ccc(C(C)(C)C)cc43)c21 ; Cc1ccccc1N1c2cc3sc4ccc(C(C)(C)C)cc4c3cc2B2c3cc4c(cc3N(c3ccc5c(c3)C(C)(C)CCC5(C)C)c3cc(C5CCCCC5)cc1c32)C(C)(C)CCC4(C)C]

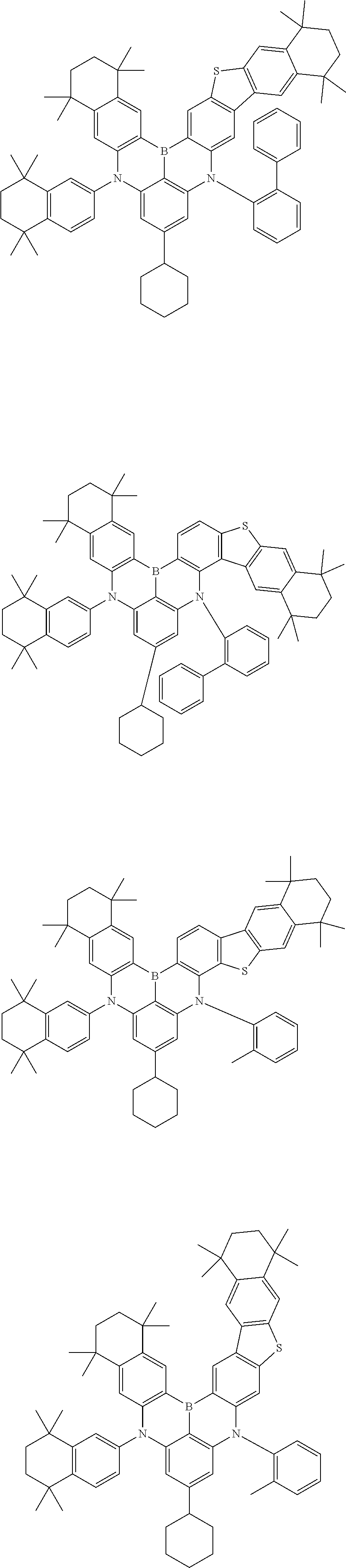

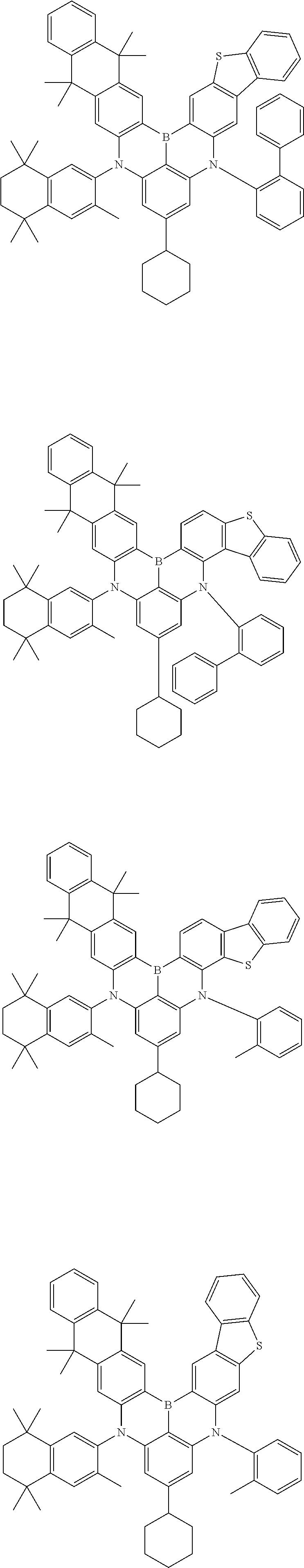 [SMILES: Cc1cc2c(cc1N1c3cc4c(cc3B3c5cc6sc7ccccc7c6cc5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5ccccc5C)c5cc(C6CCCCC6)cc1c53)C(C)(C)c1ccccc1C4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(C5CCCCC5)cc1c32)C(C)(C)c1ccccc1C4(C)C]

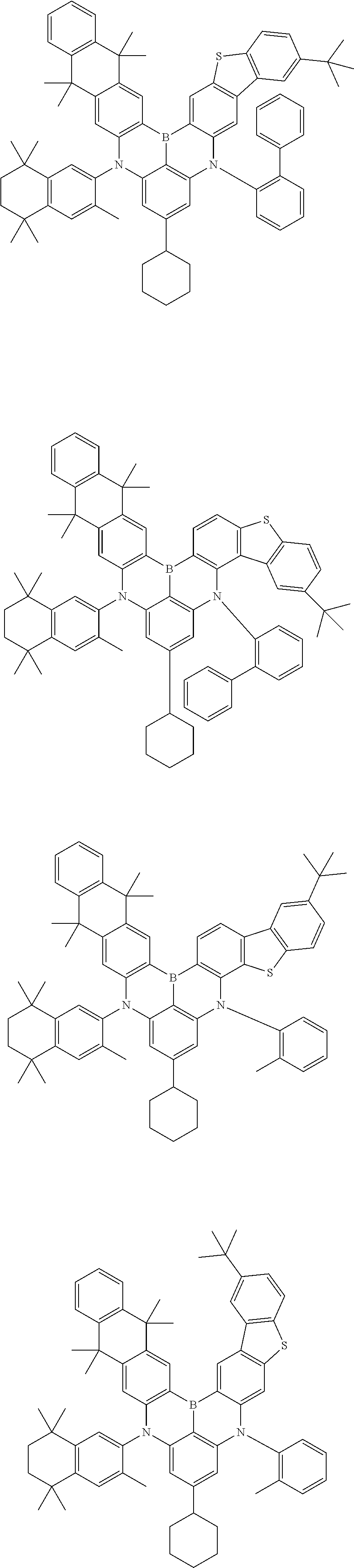

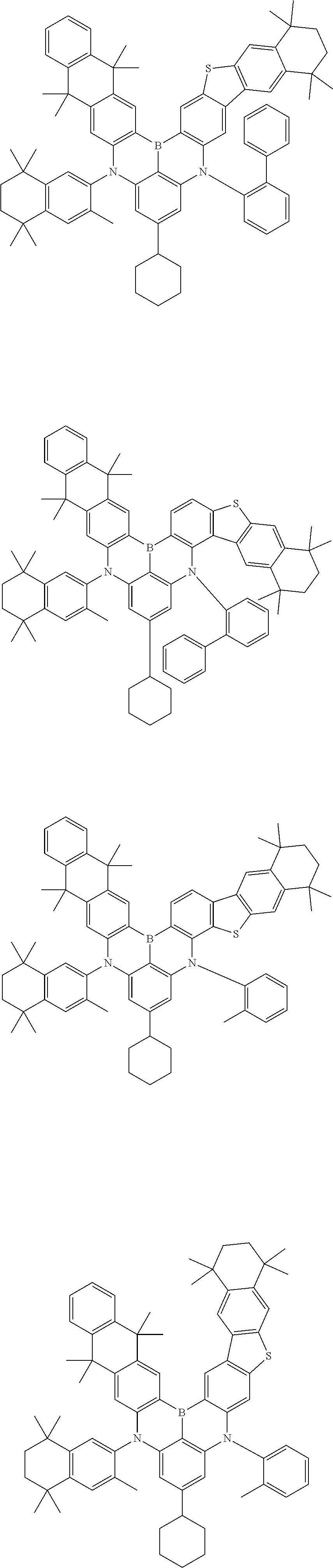

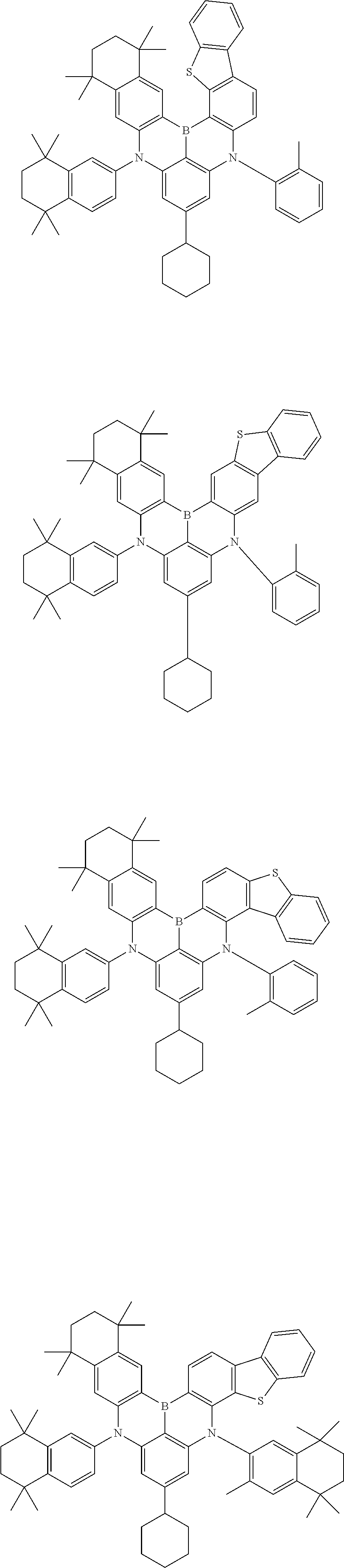 [SMILES: Cc1ccccc1N1c2cc(C3CCCCC3)cc3c2B(c2cc4c(cc2N3c2ccc3c(c2)C(C)(C)CCC3(C)C)C(C)(C)CCC4(C)C)c2c1ccc1c2sc2ccccc21 ; Cc1ccccc1N1c2cc3c(cc2B2c4cc5c(cc4N(c4ccc6c(c4)C(C)(C)CCC6(C)C)c4cc(C6CCCCC6)cc1c42)C(C)(C)CCC5(C)C)sc1ccccc13 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3sc4ccccc4c3c21 ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(sc5ccccc54)c31)C(C)(C)CCC2(C)C]

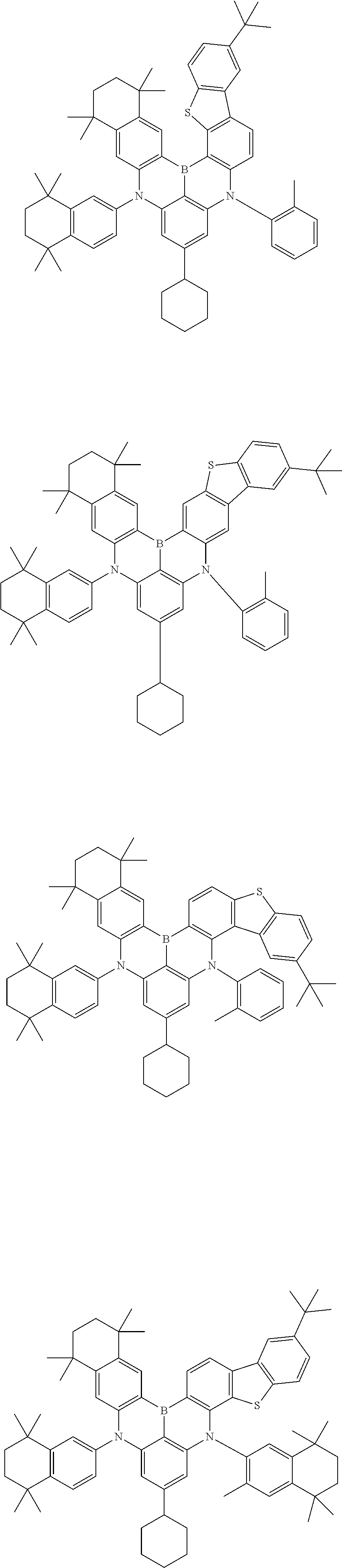 [SMILES: Cc1ccccc1N1c2cc(C3CCCCC3)cc3c2B(c2cc4c(cc2N3c2ccc3c(c2)C(C)(C)CCC3(C)C)C(C)(C)CCC4(C)C)c2c1ccc1c2sc2ccc(C(C)(C)C)cc21 ; Cc1ccccc1N1c2cc3c(cc2B2c4cc5c(cc4N(c4ccc6c(c4)C(C)(C)CCC6(C)C)c4cc(C6CCCCC6)cc1c42)C(C)(C)CCC5(C)C)sc1ccc(C(C)(C)C)cc13 ; Cc1ccccc1N1c2cc(C3CCCCC3)cc3c2B(c2cc4c(cc2N3c2ccc3c(c2)C(C)(C)CCC3(C)C)C(C)(C)CCC4(C)C)c2ccc3sc4ccc(C(C)(C)C)cc4c3c21 ; Cc1cc2c(cc1N1c3cc(C4CCCCC4)cc4c3B(c3cc5c(cc3N4c3ccc4c(c3)C(C)(C)CCC4(C)C)C(C)(C)CCC5(C)C)c3ccc4c(sc5ccc(C(C)(C)C)cc54)c31)C(C)(C)CCC2(C)C]

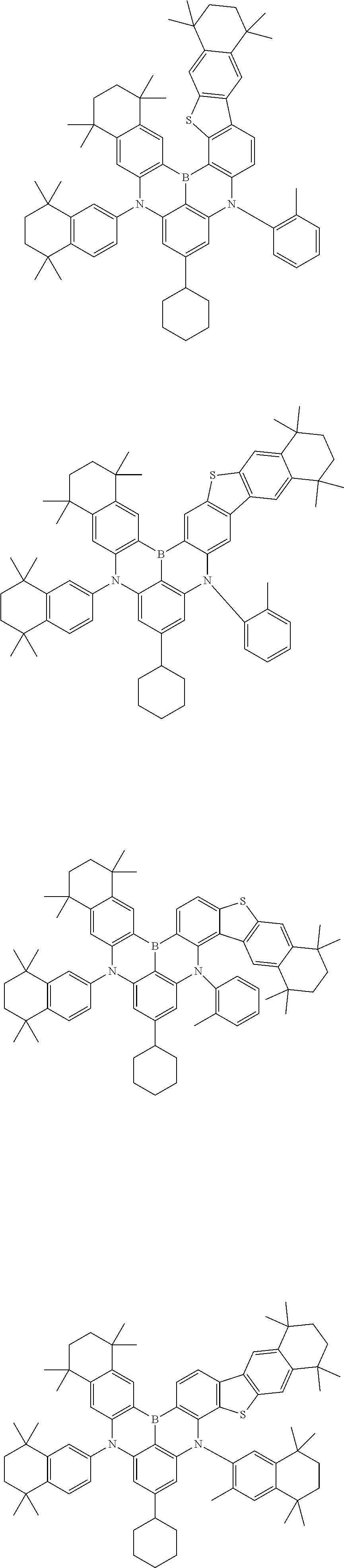

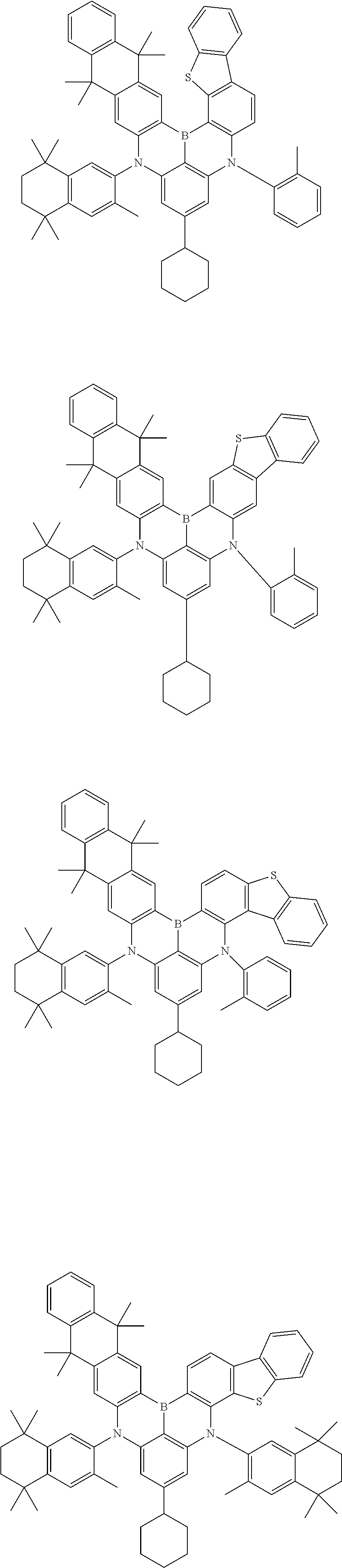 [SMILES: Cc1cc2c(cc1N1c3cc4c(cc3B3c5c1cc(C1CCCCC1)cc5N(c1ccccc1C)c1ccc5c(sc6ccccc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)c1ccccc1C5(C)C)sc1ccccc13 ; Cc1cc2c(cc1N1c3cc4c(cc3B3c5ccc6sc7ccccc7c6c5N(c5ccccc5C)c5cc(C6CCCCC6)cc1c53)C(C)(C)c1ccccc1C4(C)C)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(C6CCCCC6)cc1c53)C(C)(C)c1ccccc1C4(C)C)C(C)(C)CCC2(C)C]

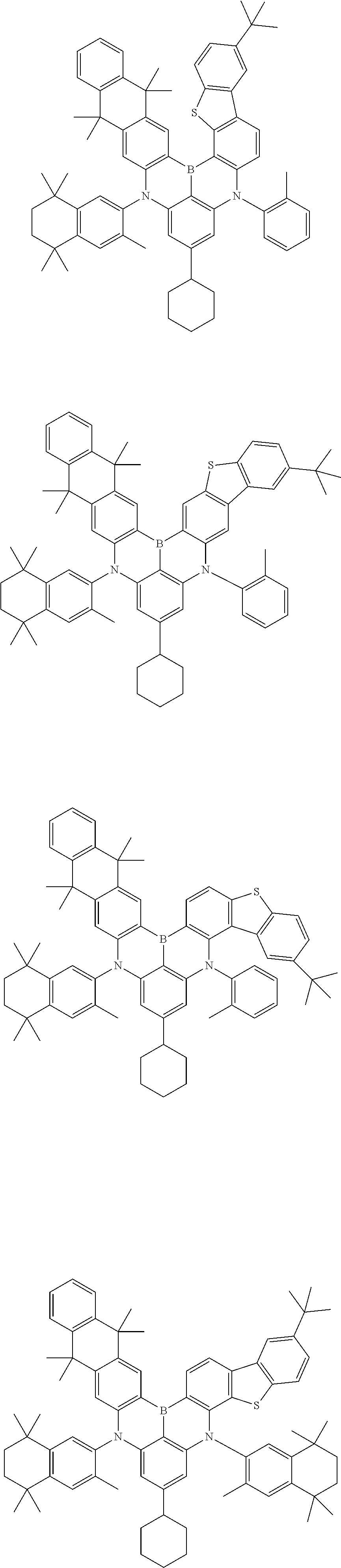

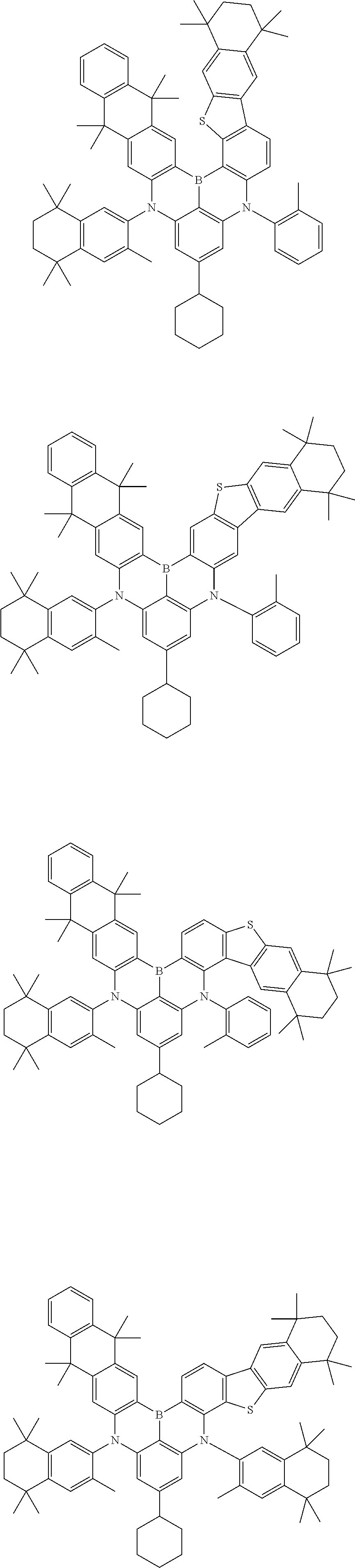

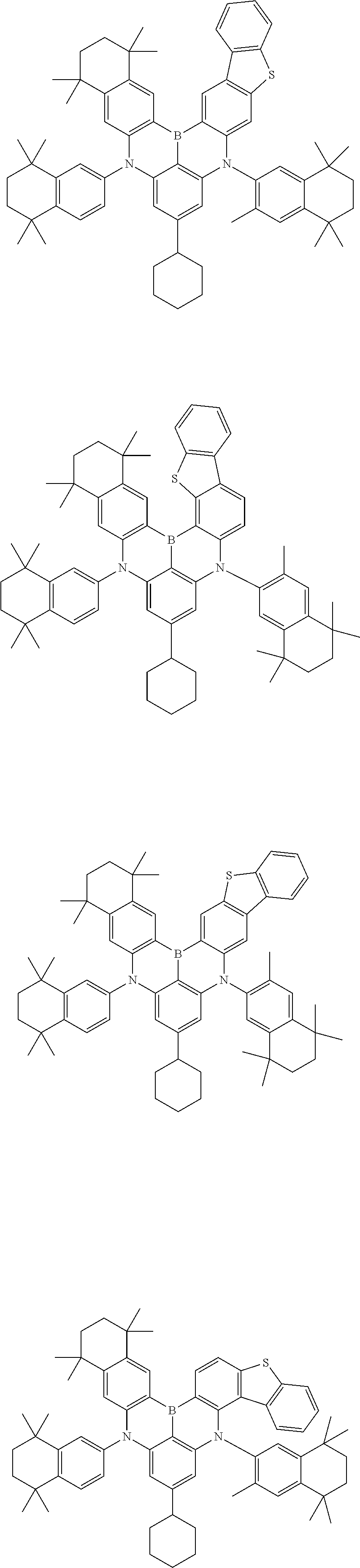

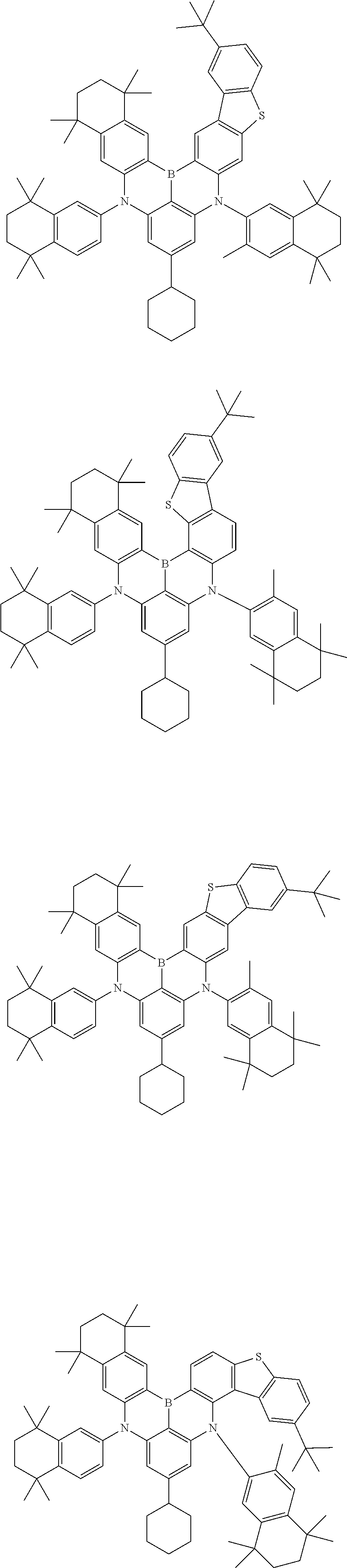

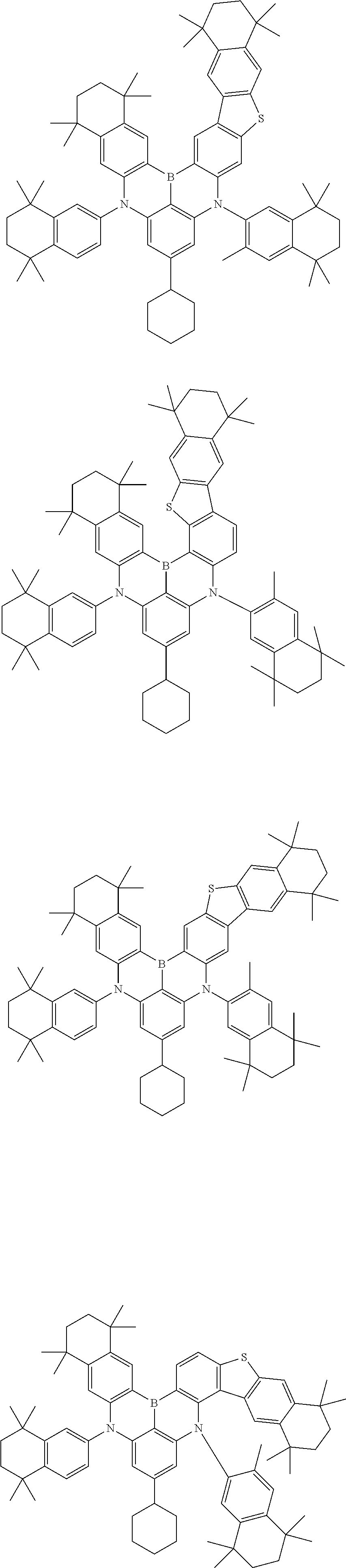

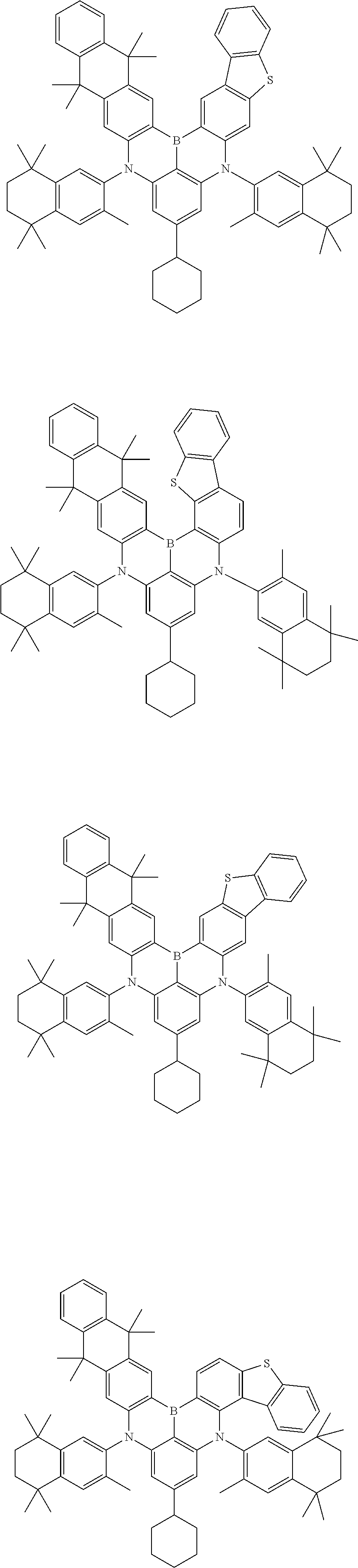

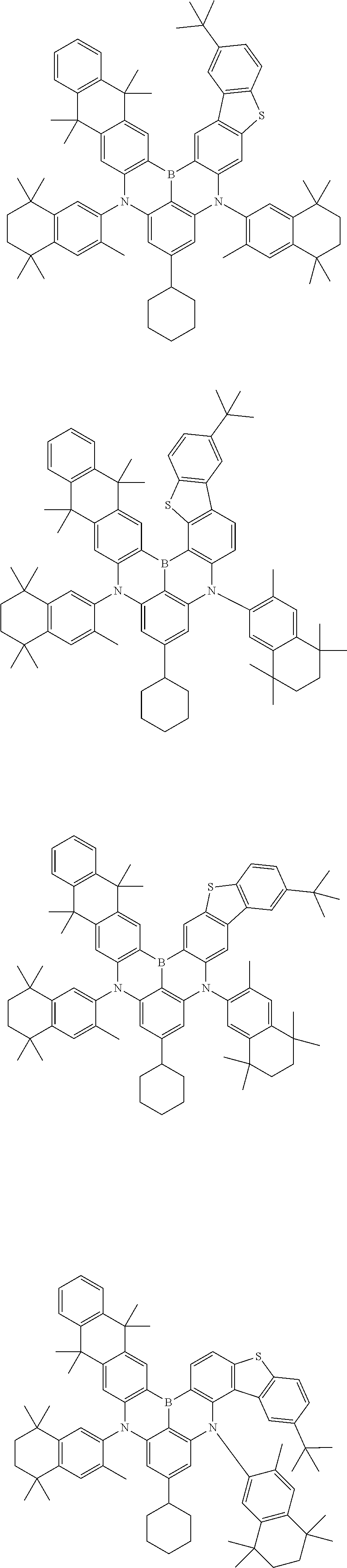

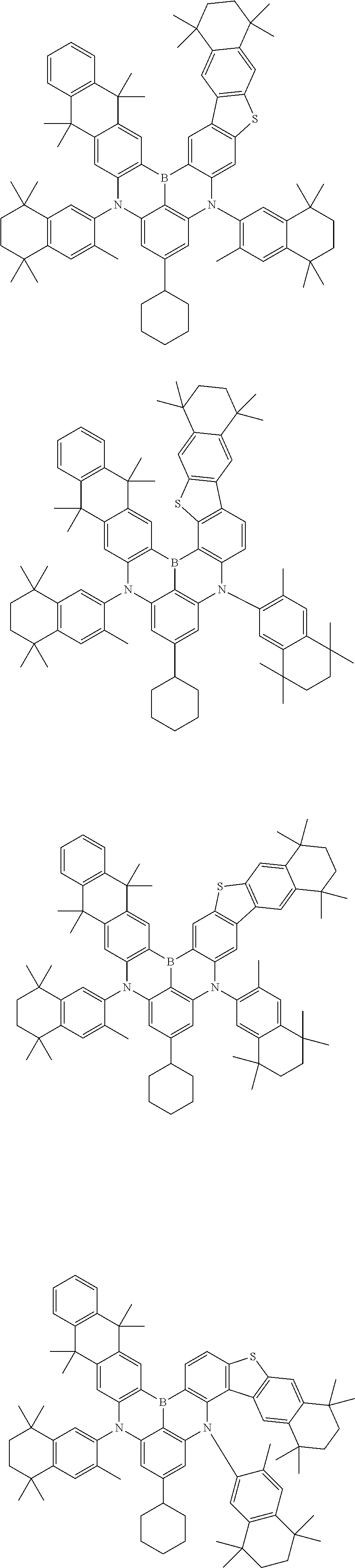

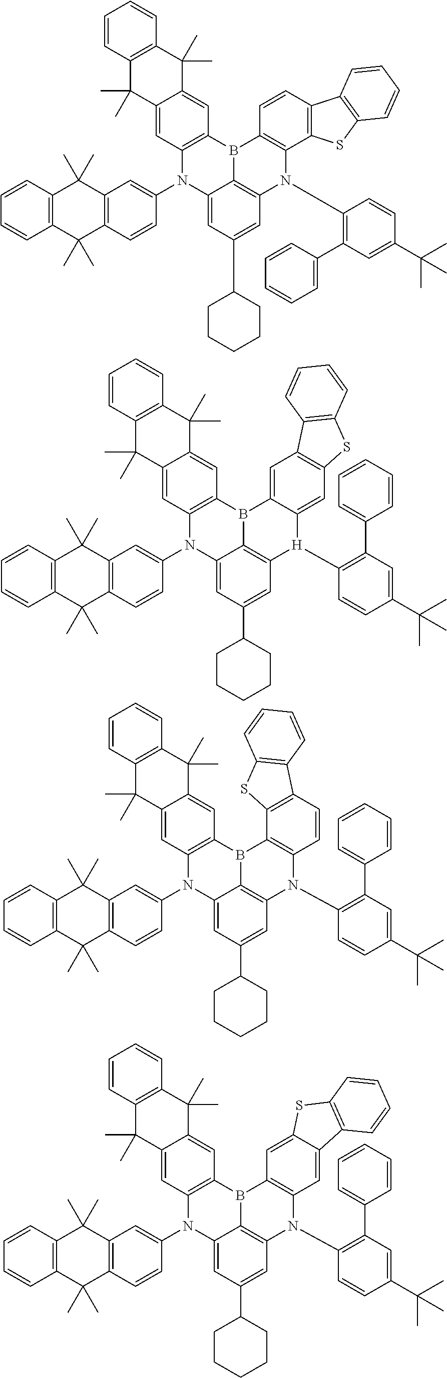

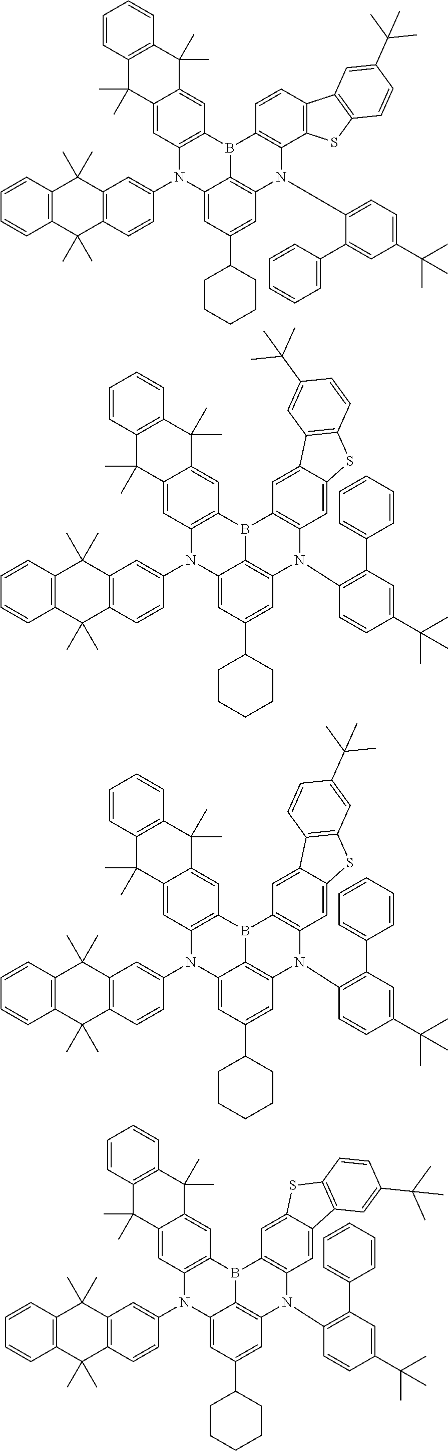

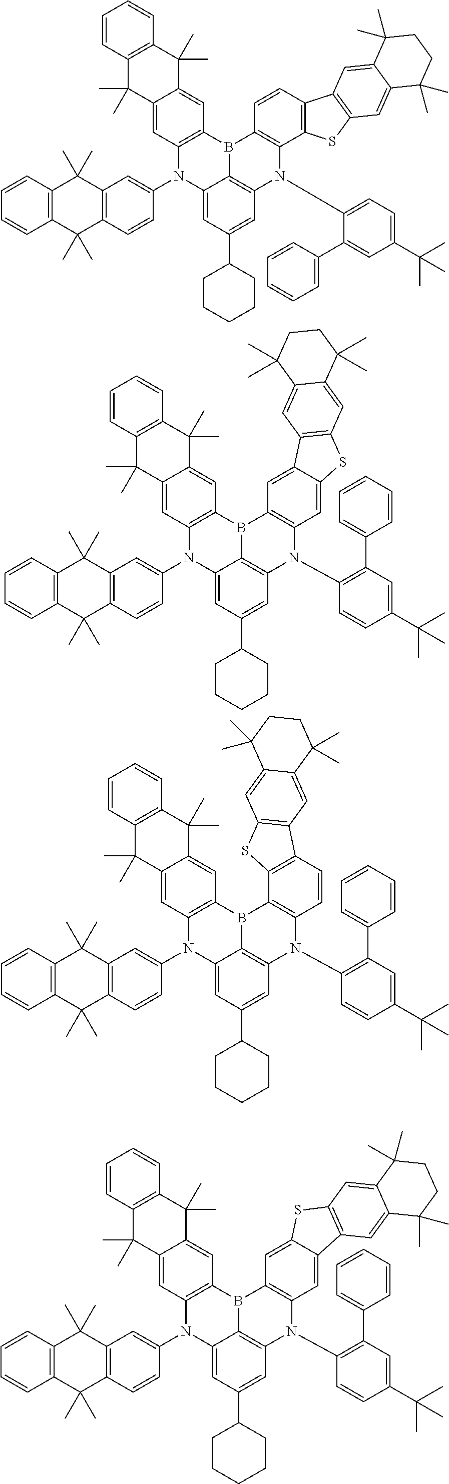

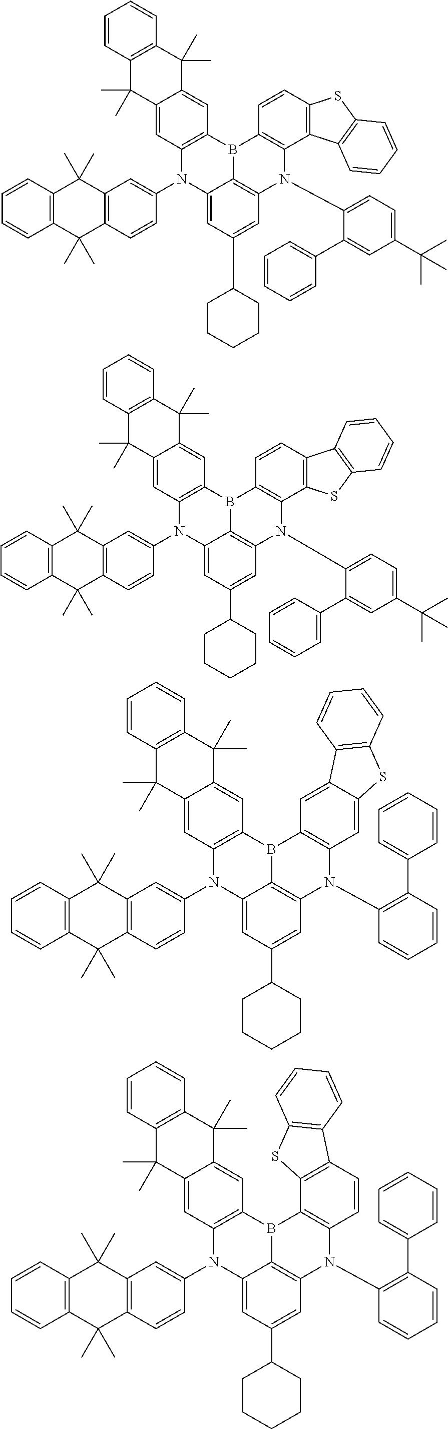

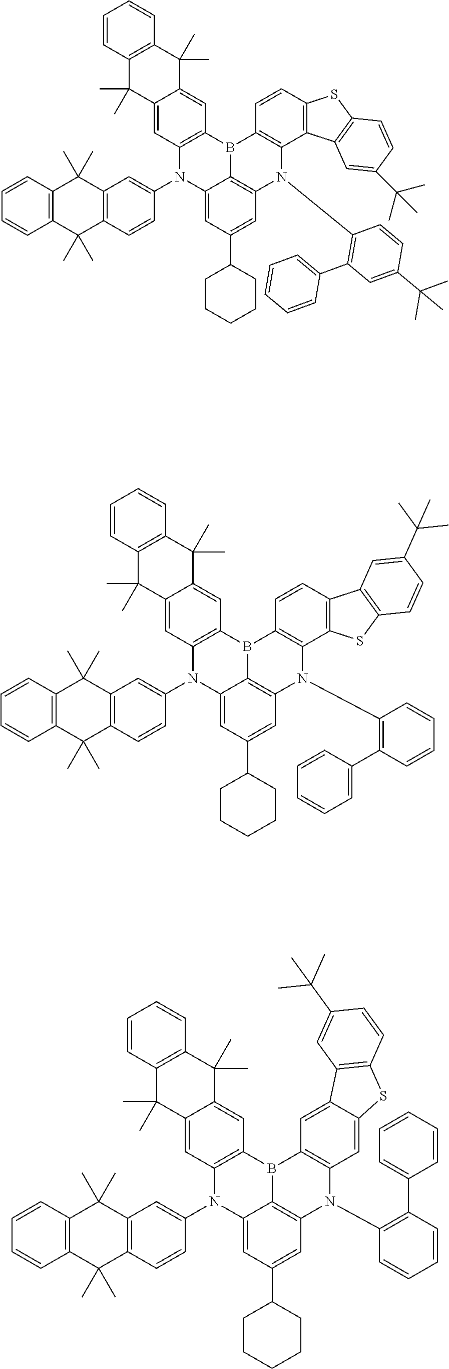 [SMILES: CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4sc5ccc(C(C)(C)C)cc5c4c32)c(-c2ccccc2)c1 ; CC(C)(C)c1ccc2sc3c4c(ccc3c2c1)B1c2cc3c(cc2N(c2ccc5c(c2)C(C)(C)c2ccccc2C5(C)C)c2cc(C5CCCCC5)cc(c21)N4c1ccccc1-c1ccccc1)C(C)(C)c1ccccc1C3(C)C ; CC(C)(C)c1ccc2sc3cc4c(cc3c2c1)B1c2cc3c(cc2N(c2ccc5c(c2)C(C)(C)c2ccccc2C5(C)C)c2cc(C5CCCCC5)cc(c21)N4c1ccccc1-c1ccccc1)C(C)(C)c1ccccc1C3(C)C]

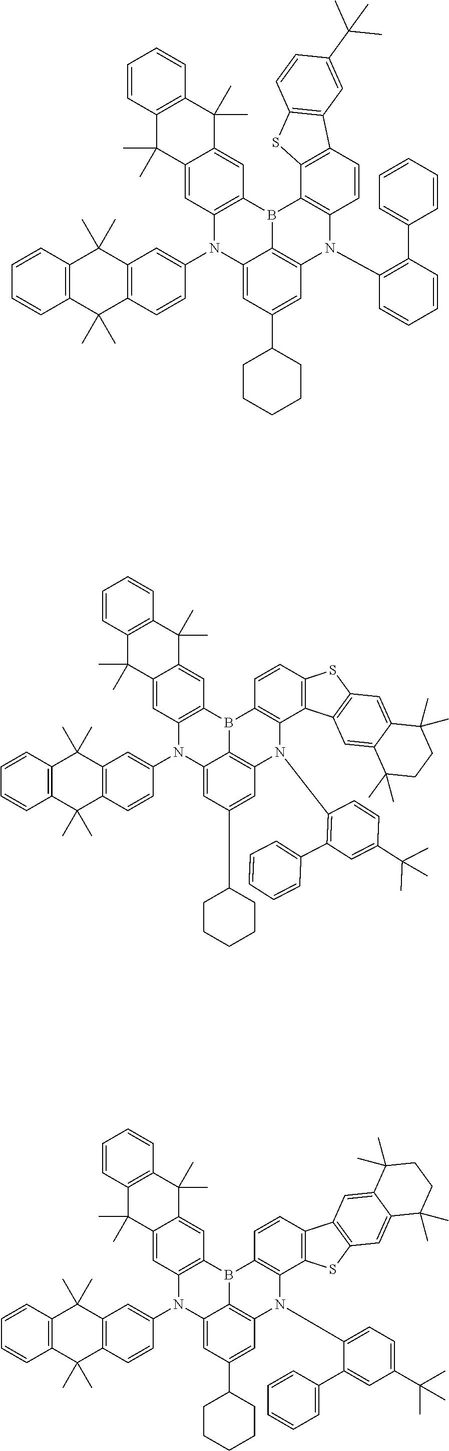 [SMILES: CC(C)(C)c1ccc2sc3c4c(ccc3c2c1)N(c1ccccc1-c1ccccc1)c1cc(C2CCCCC2)cc2c1B4c1cc3c(cc1N2c1ccc2c(c1)C(C)(C)c1ccccc1C2(C)C)C(C)(C)c1ccccc1C3(C)C ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4sc5cc6c(cc5c4c32)C(C)(C)CCC6(C)C)c(-c2ccccc2)c1 ; CC(C)(C)c1ccc(N2c3cc(C4CCCCC4)cc4c3B(c3cc5c(cc3N4c3ccc4c(c3)C(C)(C)c3ccccc3C4(C)C)C(C)(C)c3ccccc3C5(C)C)c3ccc4c(sc5cc6c(cc54)C(C)(C)CCC6(C)C)c32)c(-c2ccccc2)c1]

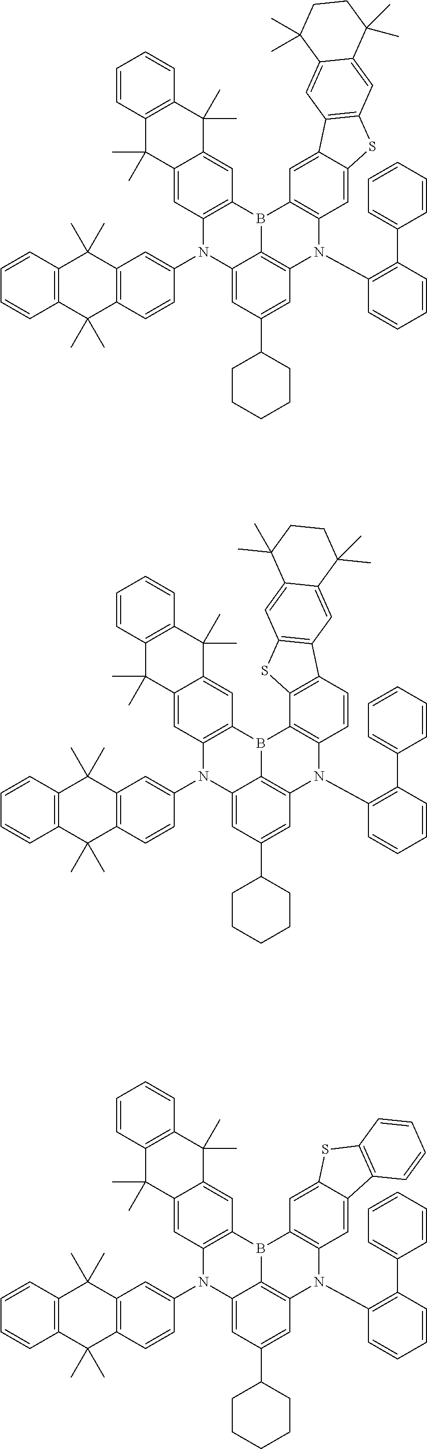 [SMILES: CC1(C)CCC(C)(C)c2cc3c(cc21)sc1cc2c(cc13)B1c3cc4c(cc3N(c3ccc5c(c3)C(C)(C)c3ccccc3C5(C)C)c3cc(C5CCCCC5)cc(c31)N2c1ccccc1-c1ccccc1)C(C)(C)c1ccccc1C4(C)C ; CC1(C)CCC(C)(C)c2cc3c(cc21)sc1c2c(ccc13)N(c1ccccc1-c1ccccc1)c1cc(C3CCCCC3)cc3c1B2c1cc2c(cc1N3c1ccc3c(c1)C(C)(C)c1ccccc1C3(C)C)C(C)(C)c1ccccc1C2(C)C ; CC1(C)c2ccccc2C(C)(C)c2cc(N3c4cc5c(cc4B4c6cc7sc8ccccc8c7cc6N(c6ccccc6-c6ccccc6)c6cc(C7CCCCC7)cc3c64)C(C)(C)c3ccccc3C5(C)C)ccc21]

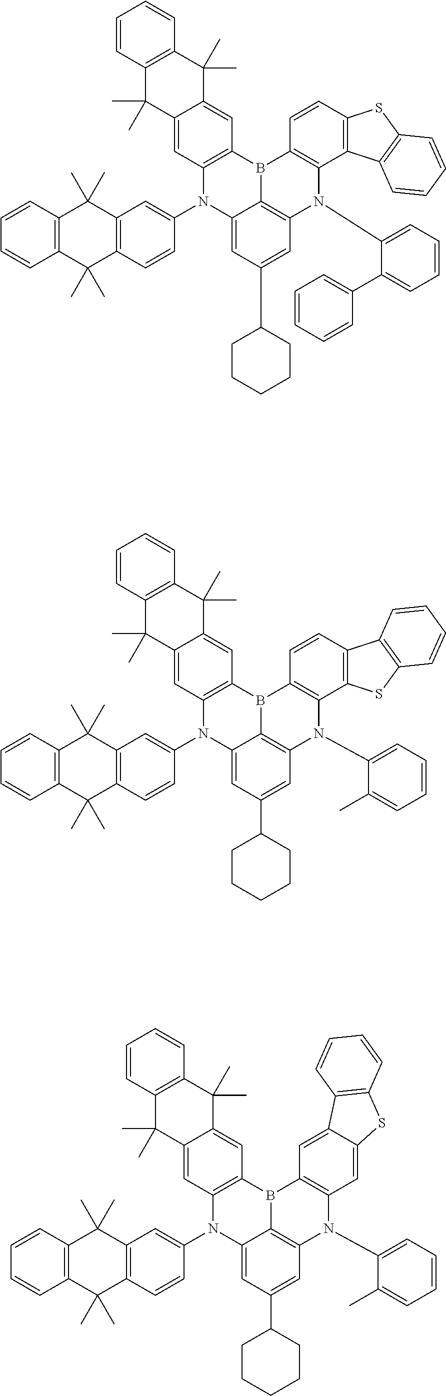 [SMILES: CC1(C)c2ccccc2C(C)(C)c2cc(N3c4cc5c(cc4B4c6ccc7sc8ccccc8c7c6N(c6ccccc6-c6ccccc6)c6cc(C7CCCCC7)cc3c64)C(C)(C)c3ccccc3C5(C)C)ccc21 ; Cc1ccccc1N1c2cc(C3CCCCC3)cc3c2B(c2cc4c(cc2N3c2ccc3c(c2)C(C)(C)c2ccccc2C3(C)C)C(C)(C)c2ccccc2C4(C)C)c2ccc3c(sc4ccccc43)c21 ; Cc1ccccc1N1c2cc3sc4ccccc4c3cc2B2c3cc4c(cc3N(c3ccc5c(c3)C(C)(C)c3ccccc3C5(C)C)c3cc(C5CCCCC5)cc1c32)C(C)(C)c1ccccc1C4(C)C]

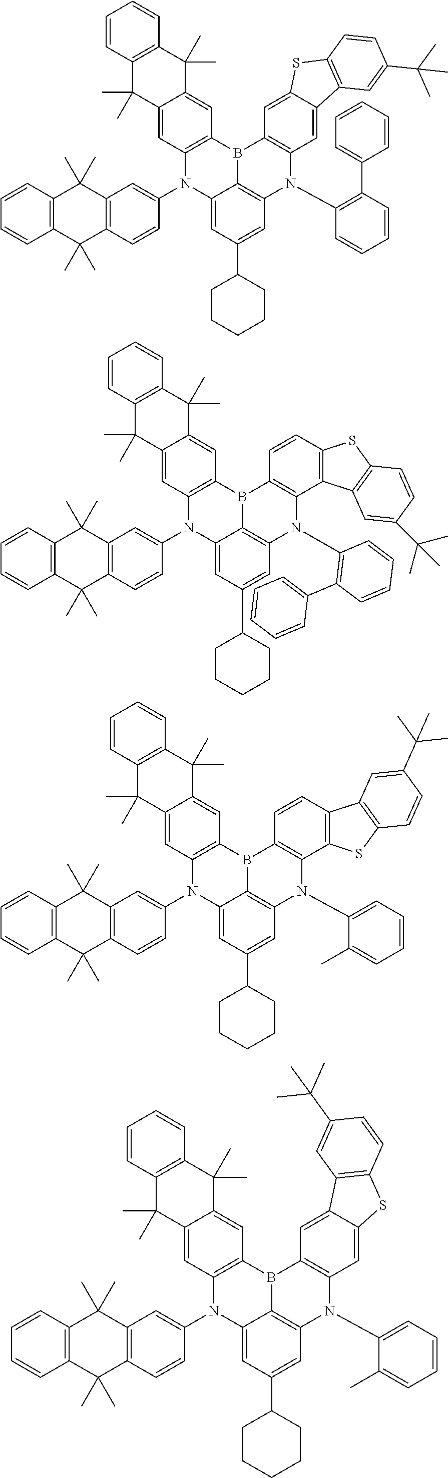

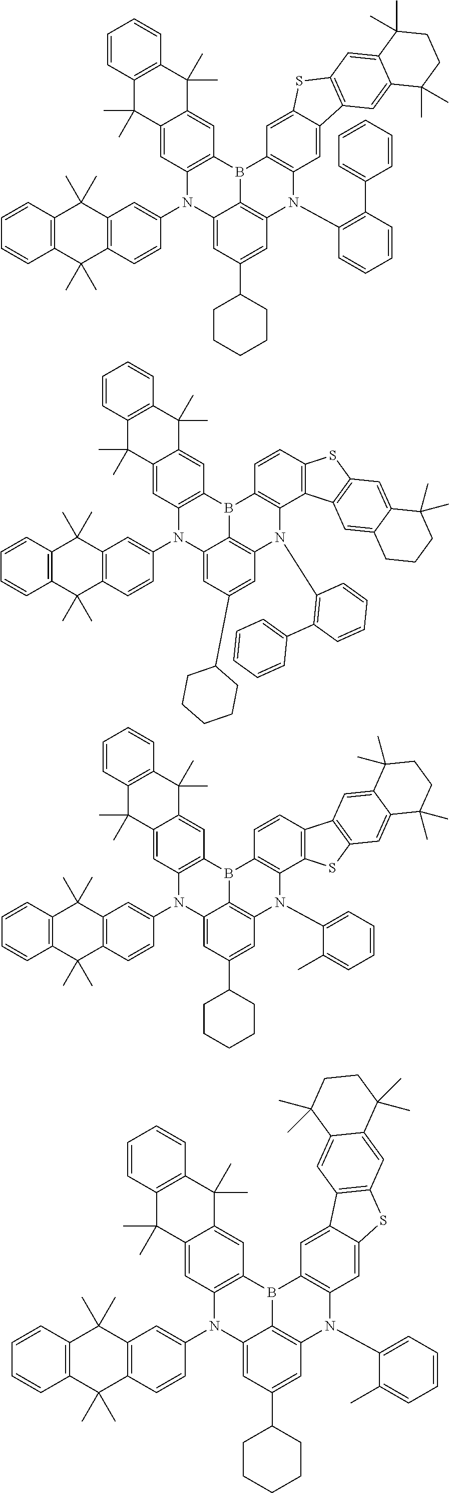

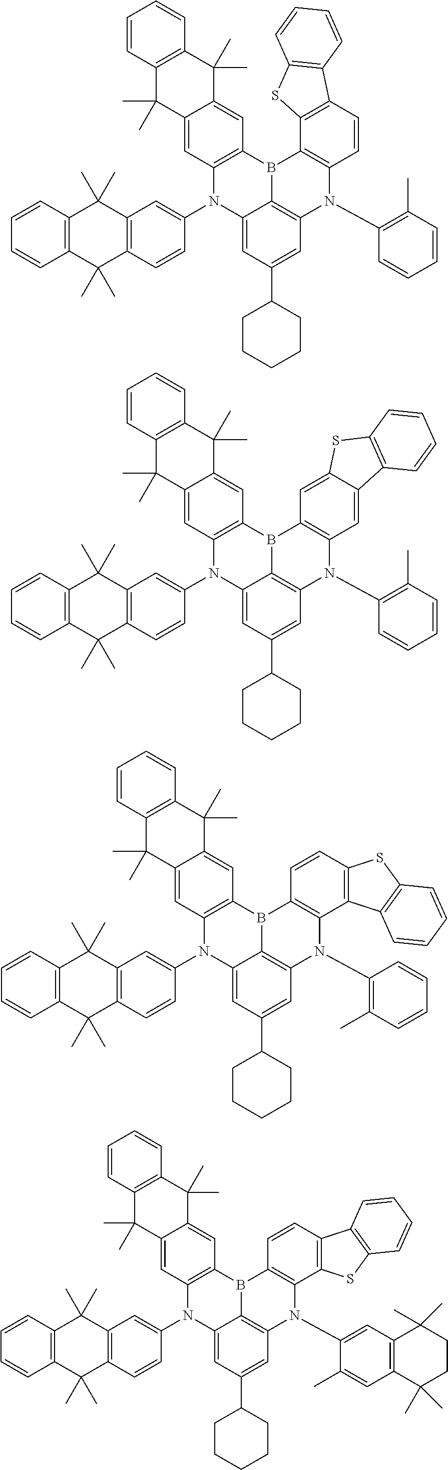

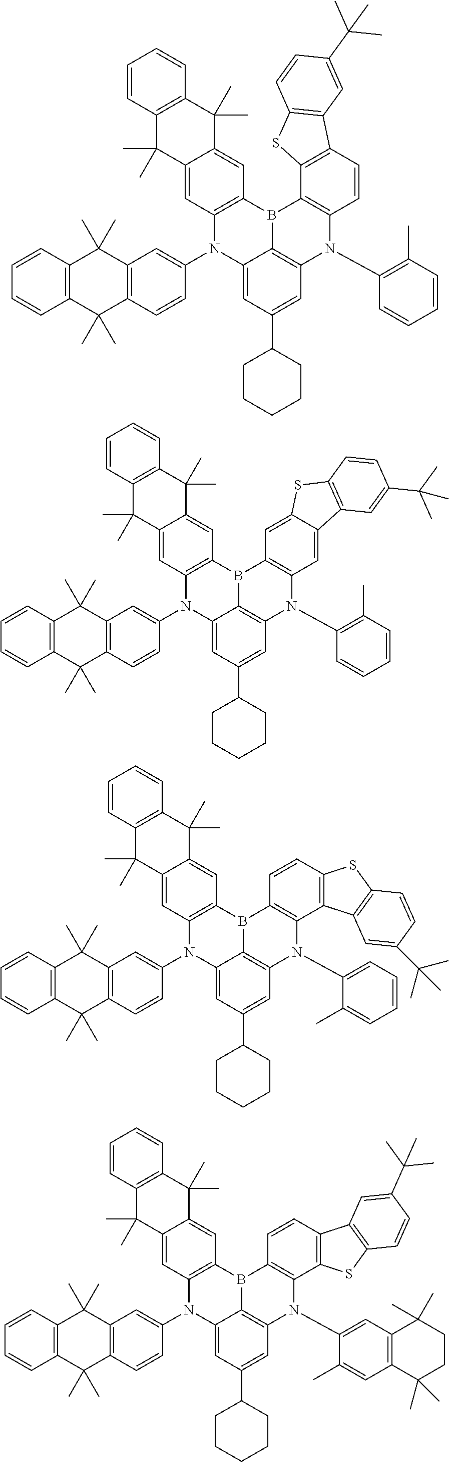

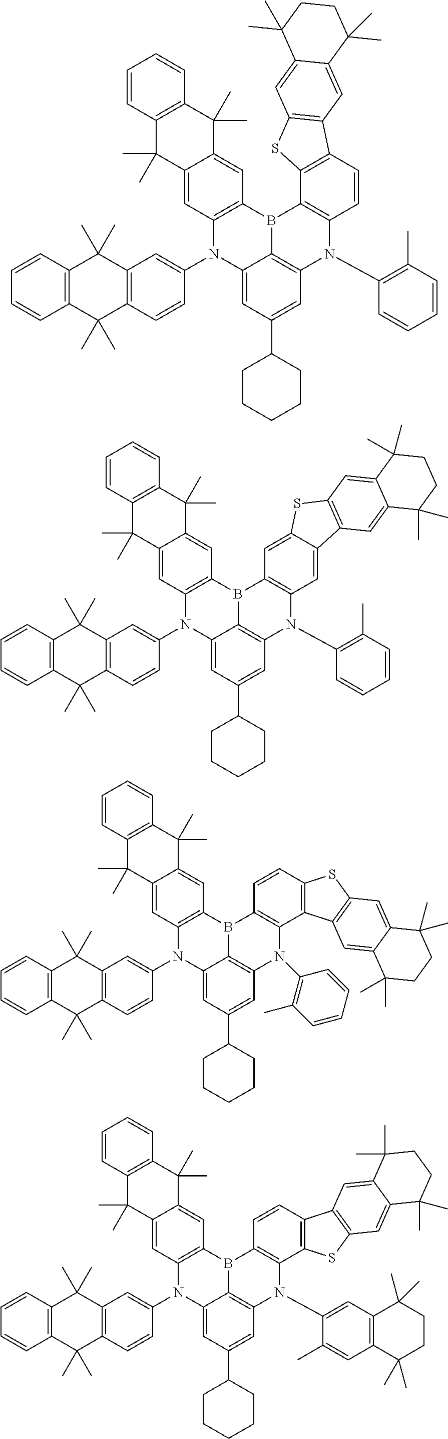

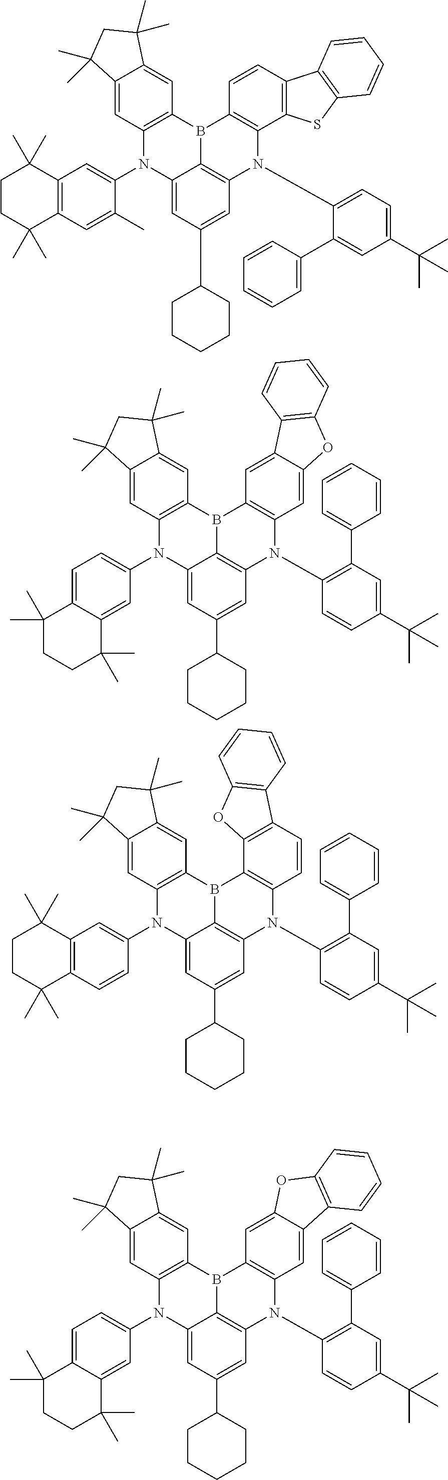

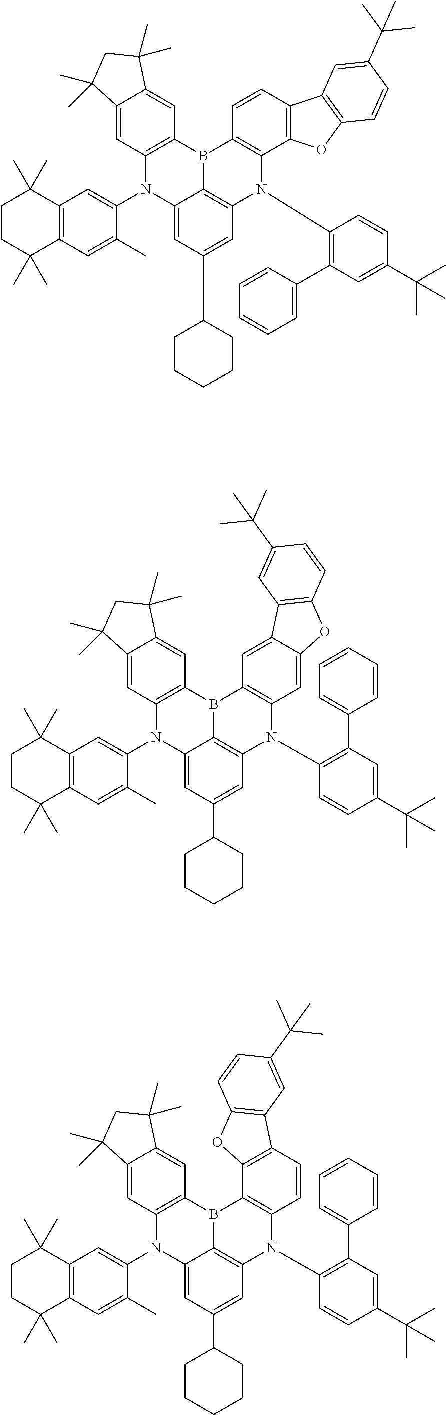 [SMILES: Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(C1CCCCC1)cc5N(c1ccc(C(C)(C)C)cc1-c1ccccc1)c1ccc5c(oc6ccc(C(C)(C)C)cc65)c13)C(C)(C)CC4(C)C)C(C)(C)CCC2(C)C]

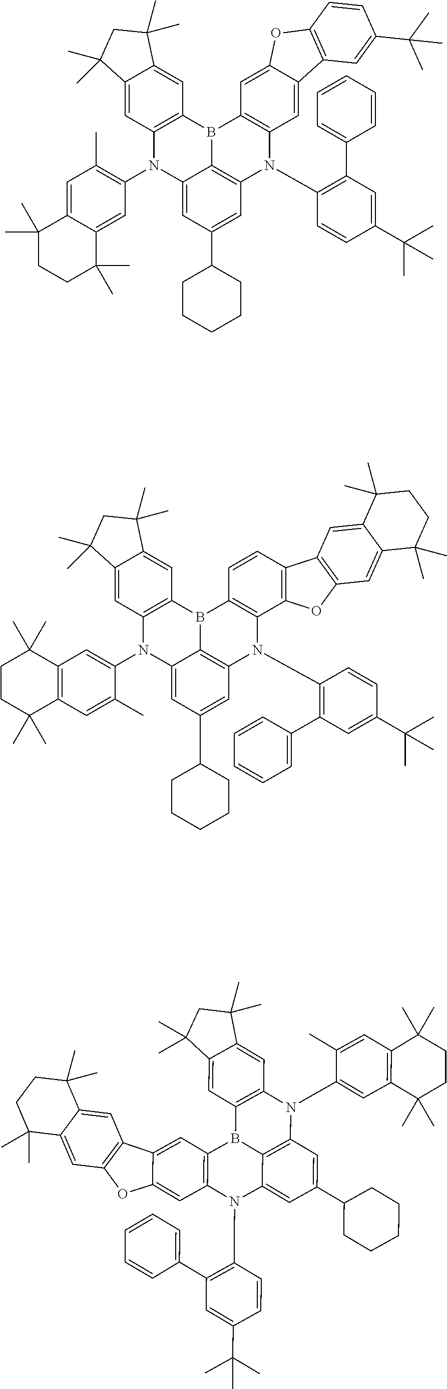

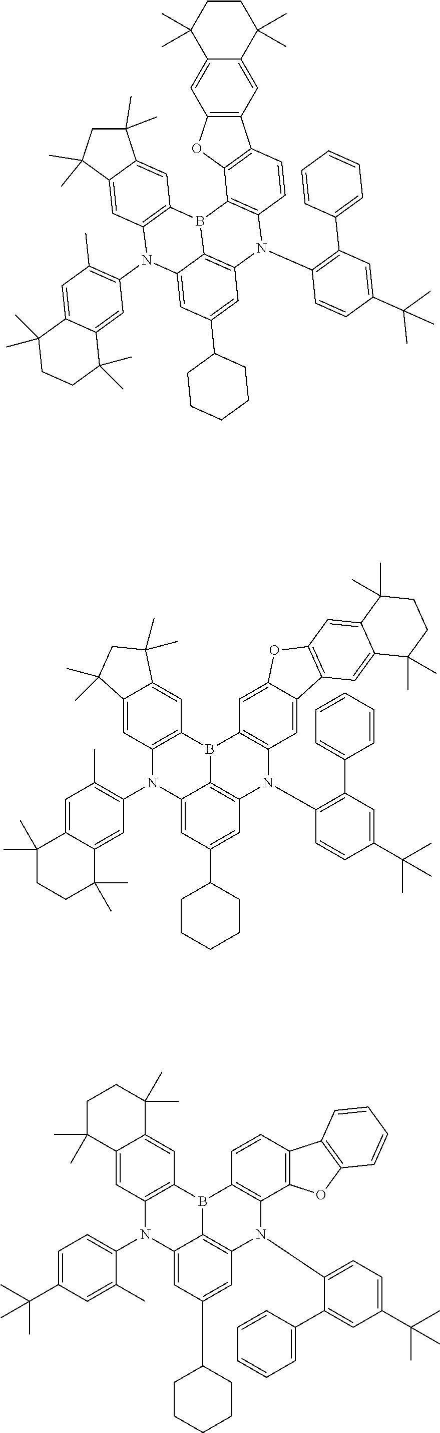

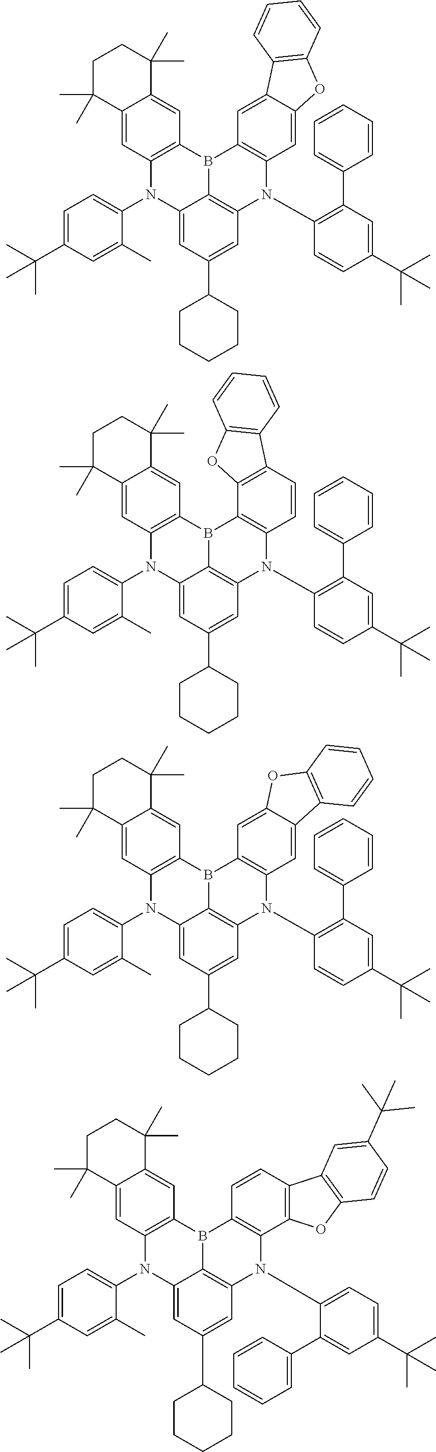

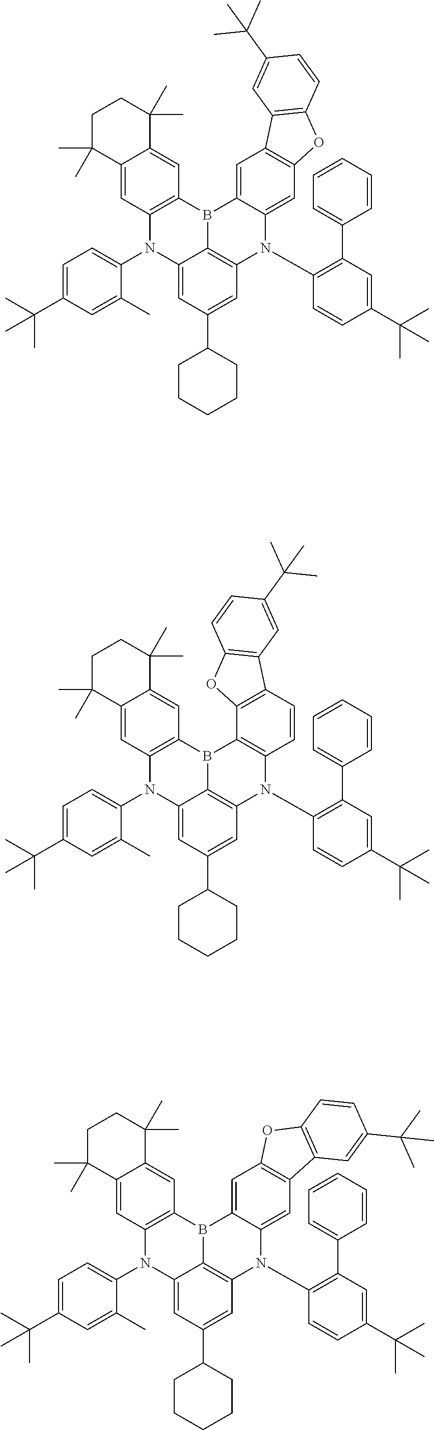

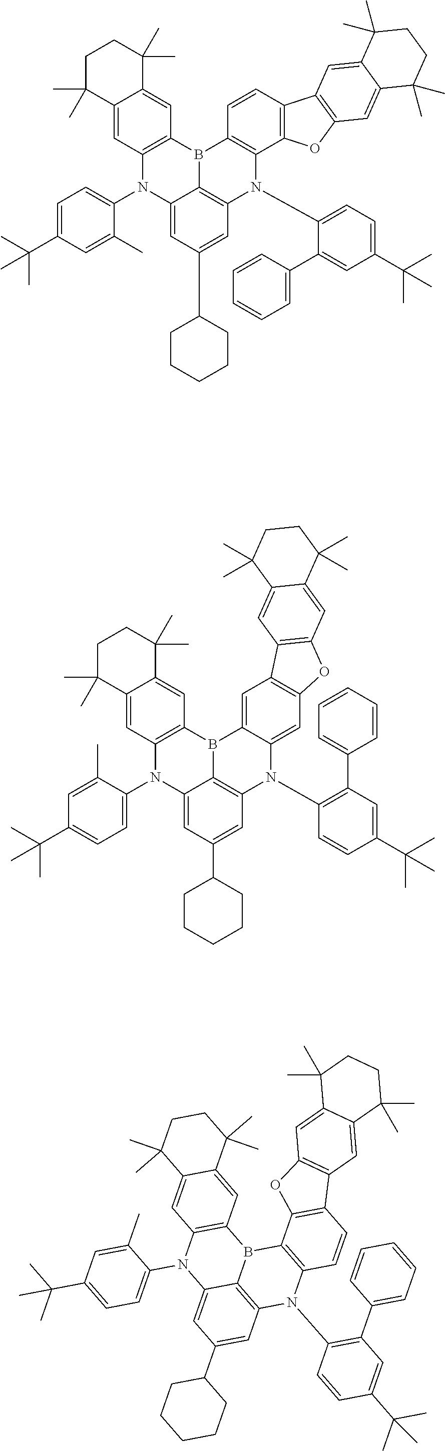

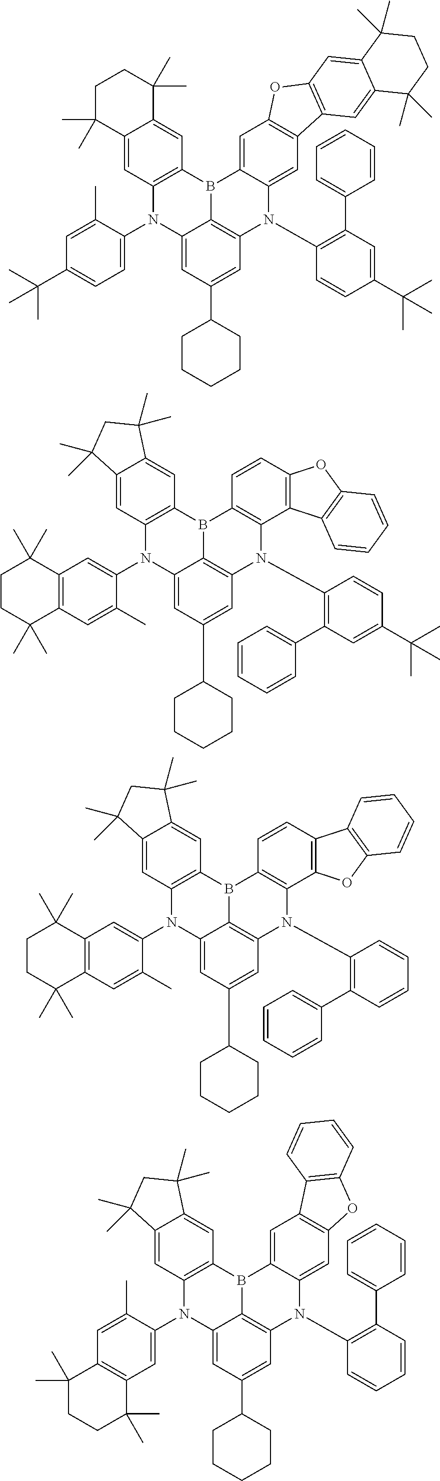

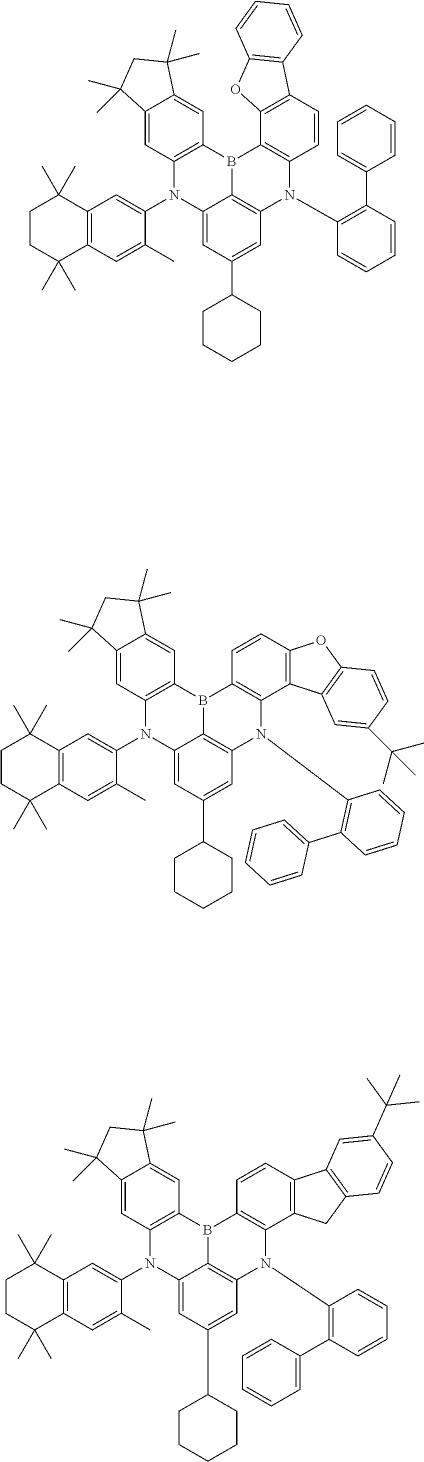 [SMILES: Cc1cc2c(cc1N1c3cc4c(cc3B3c5c1cc(C1CCCCC1)cc5N(c1ccccc1-c1ccccc1)c1ccc5c(oc6ccccc65)c13)C(C)(C)CC4(C)C)C(C)(C)CCC2(C)C ; Cc1cc2c(cc1N1c3cc4c(cc3B3c5ccc6oc7ccc(C(C)(C)C)cc7c6c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(C7CCCCC7)cc1c53)Cc1ccc(C(C)(C)C)cc1-6)C(C)(C)CC4(C)C)C(C)(C)CCC2(C)C]

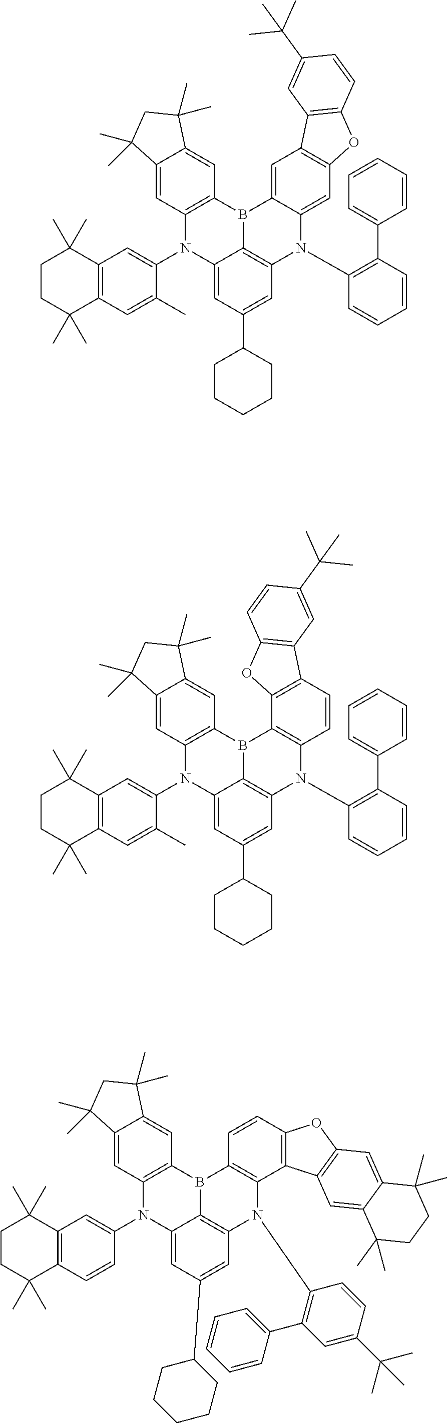 [SMILES: Cc1cc2c(cc1N1c3cc4c(cc3B3c5cc6c(cc5N(c5ccccc5-c5ccccc5)c5cc(C7CCCCC7)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(C1CCCCC1)cc5N(c1ccccc1-c1ccccc1)c1ccc5c(oc6ccc(C(C)(C)C)cc65)c13)C(C)(C)CC4(C)C)C(C)(C)CCC2(C)C ; CC(C)(C)c1ccc(N2c3cc(C4CCCCC4)cc4c3B(c3cc5c(cc3N4c3ccc4c(c3)C(C)(C)CCC4(C)C)C(C)(C)CC5(C)C)c3ccc4oc5cc6c(cc5c4c32)C(C)(C)CCC6(C)C)c(-c2ccccc2)c1]

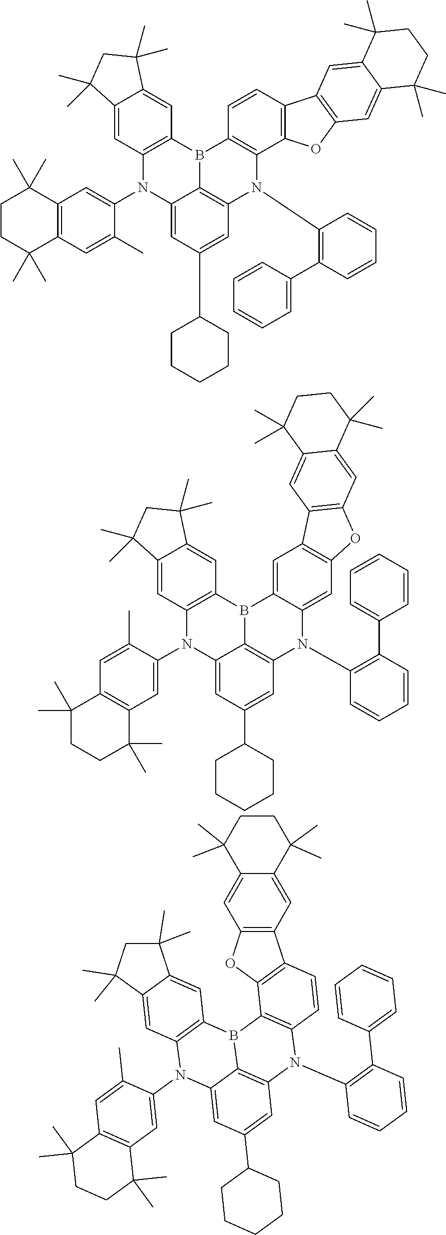

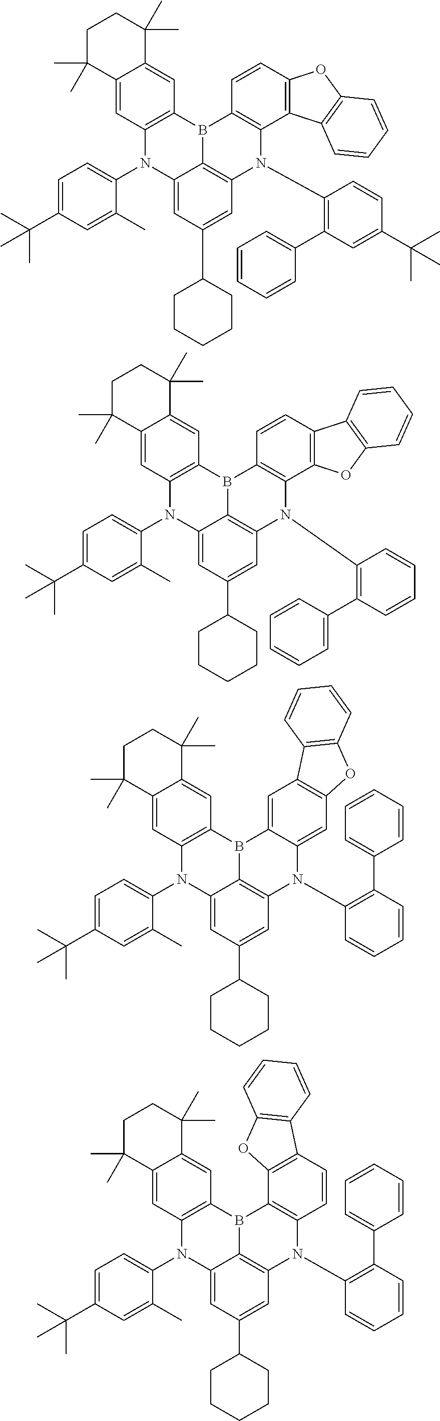

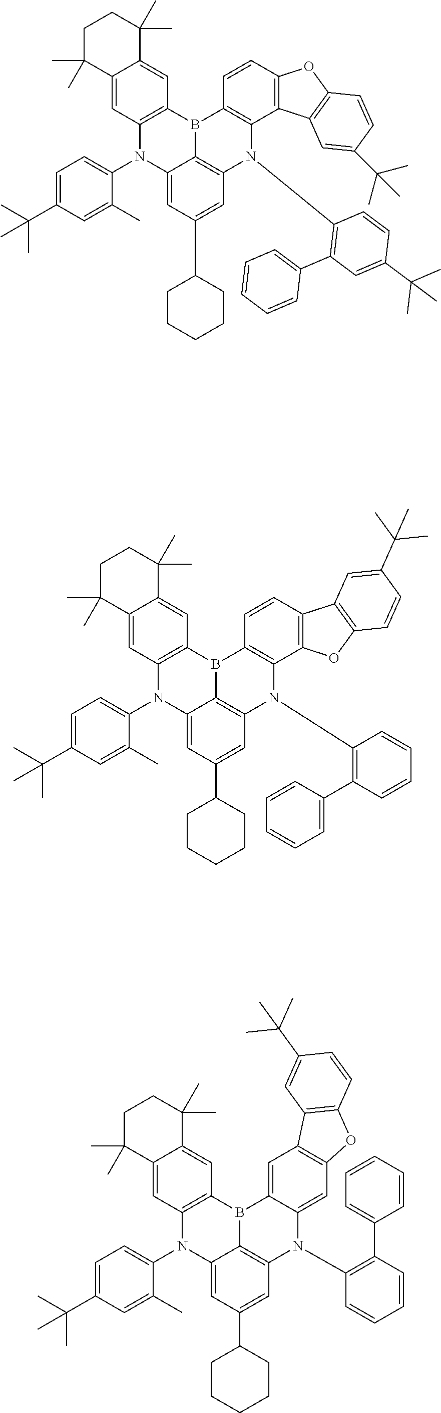

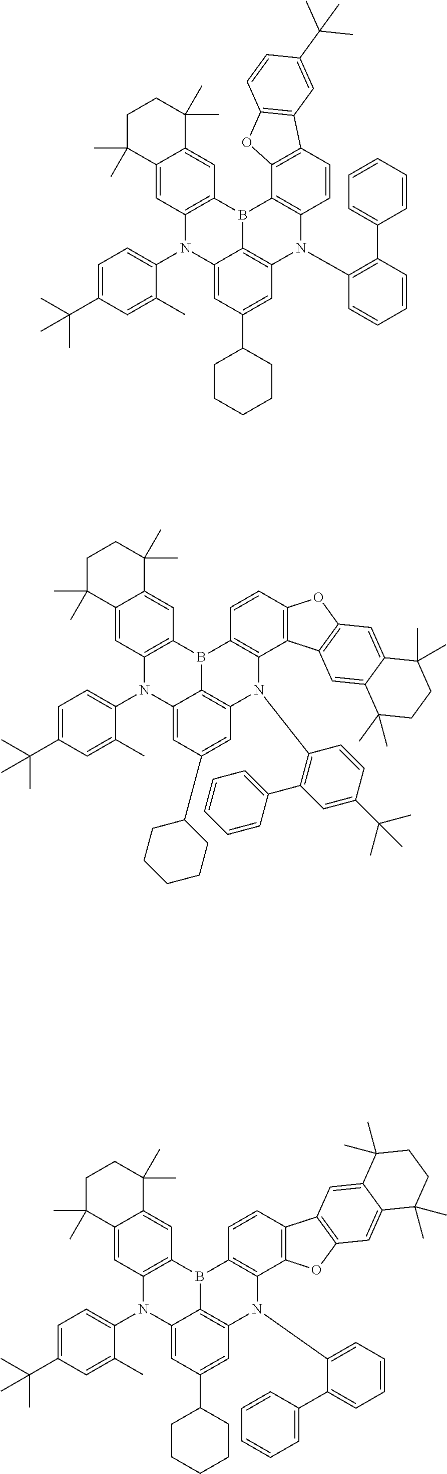

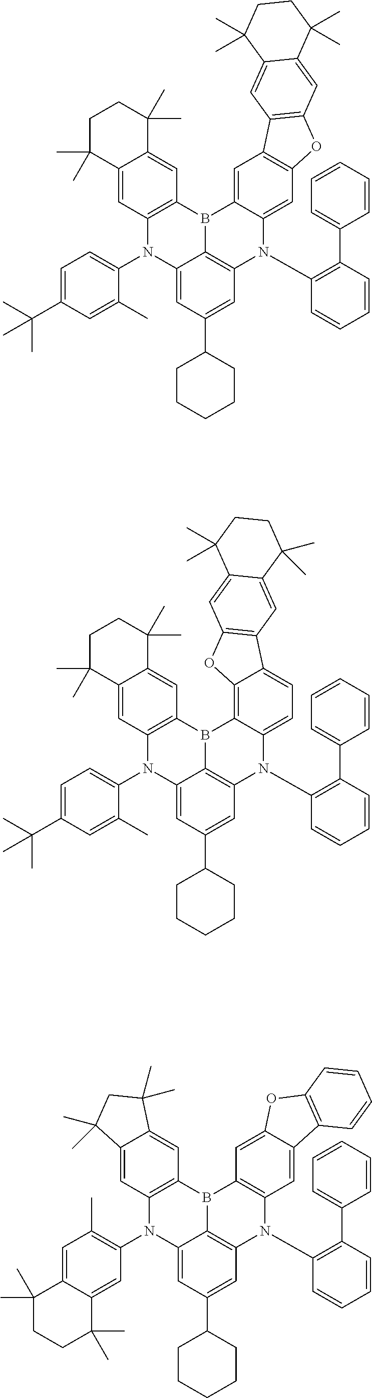 [SMILES: Cc1cc(C(C)(C)C)ccc1N1c2cc3c(cc2B2c4cc5c(cc4N(c4ccccc4-c4ccccc4)c4cc(C6CCCCC6)cc1c42)oc1cc2c(cc15)C(C)(C)CCC2(C)C)C(C)(C)CCC3(C)C ; Cc1cc(C(C)(C)C)ccc1N1c2cc3c(cc2B2c4c1cc(C1CCCCC1)cc4N(c1ccccc1-c1ccccc1)c1ccc4c(oc5cc6c(cc54)C(C)(C)CCC6(C)C)c12)C(C)(C)CCC3(C)C ; Cc1cc2c(cc1N1c3cc4c(cc3B3c5cc6oc7ccccc7c6cc5N(c5ccccc5-c5ccccc5)c5cc(C6CCCCC6)cc1c53)C(C)(C)CC4(C)C)C(C)(C)CCC2(C)C]

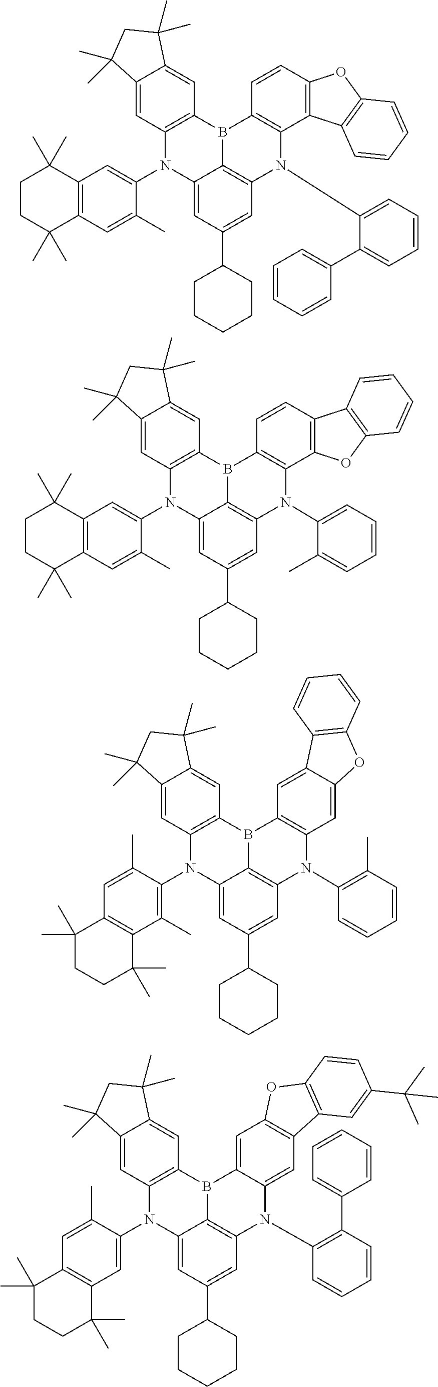

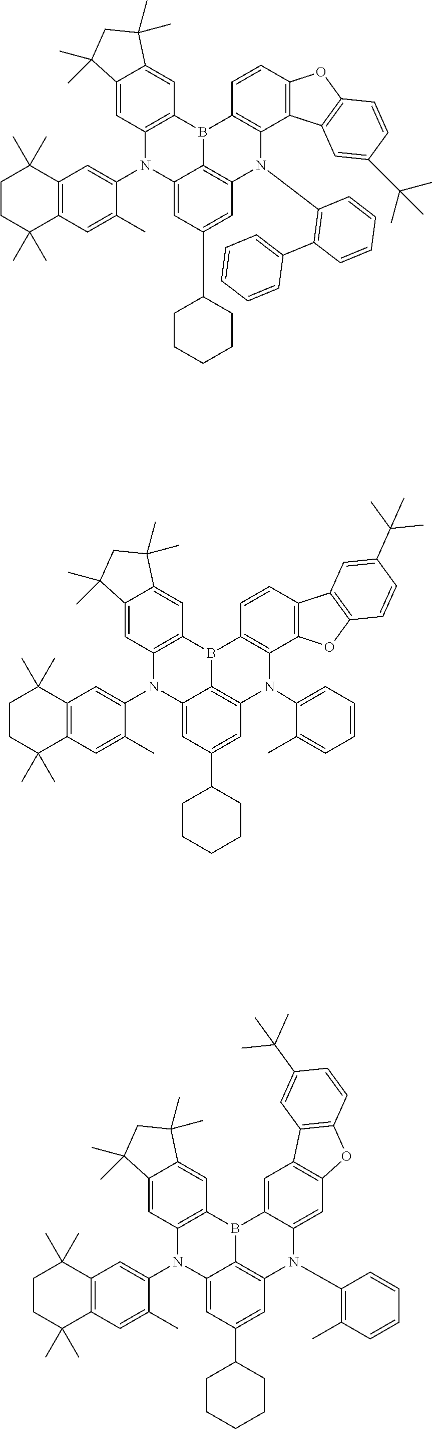 [SMILES: Cc1cc2c(cc1N1c3cc4c(cc3B3c5ccc6oc7ccc(C(C)(C)C)cc7c6c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5ccccc5C)c5cc(C6CCCCC6)cc1c53)C(C)(C)CC4(C)C)C(C)(C)CCC2(C)C ; Cc1ccccc1N1c2cc3oc4ccc(C(C)(C)C)cc4c3cc2B2c3cc4c(cc3N(c3cc5c(cc3C)C(C)(C)CCC5(C)C)c3cc(C5CCCCC5)cc1c32)C(C)(C)CC4(C)C]

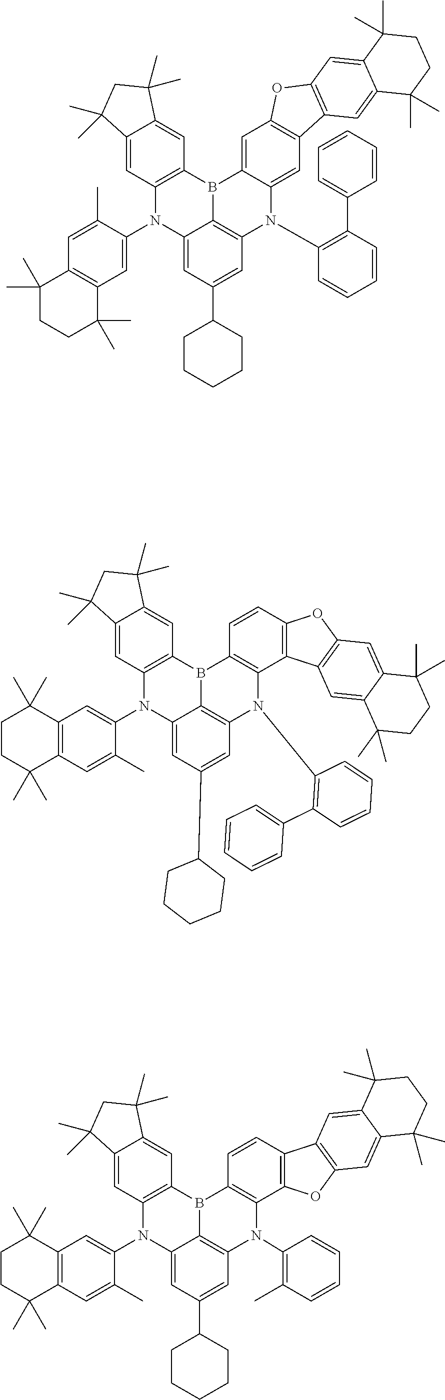

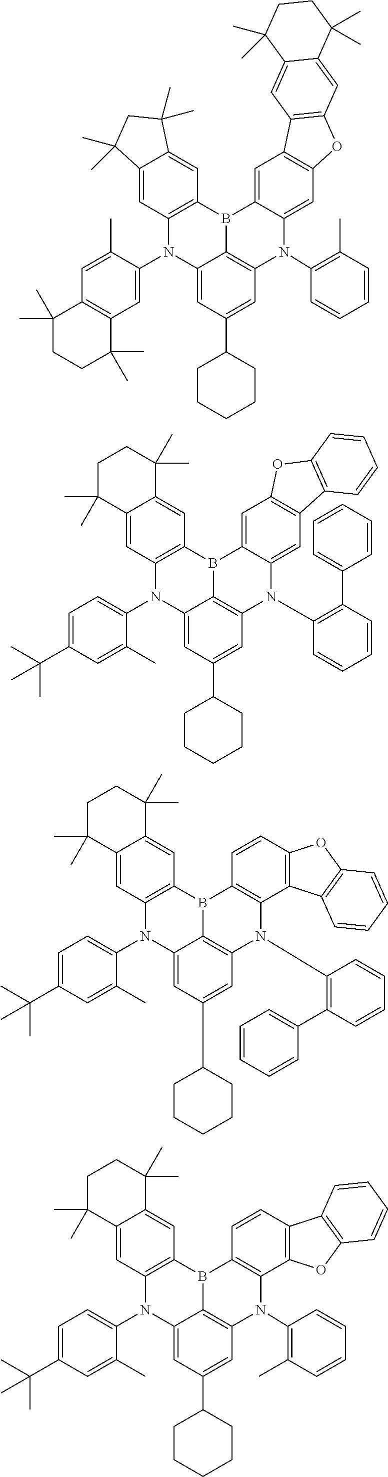

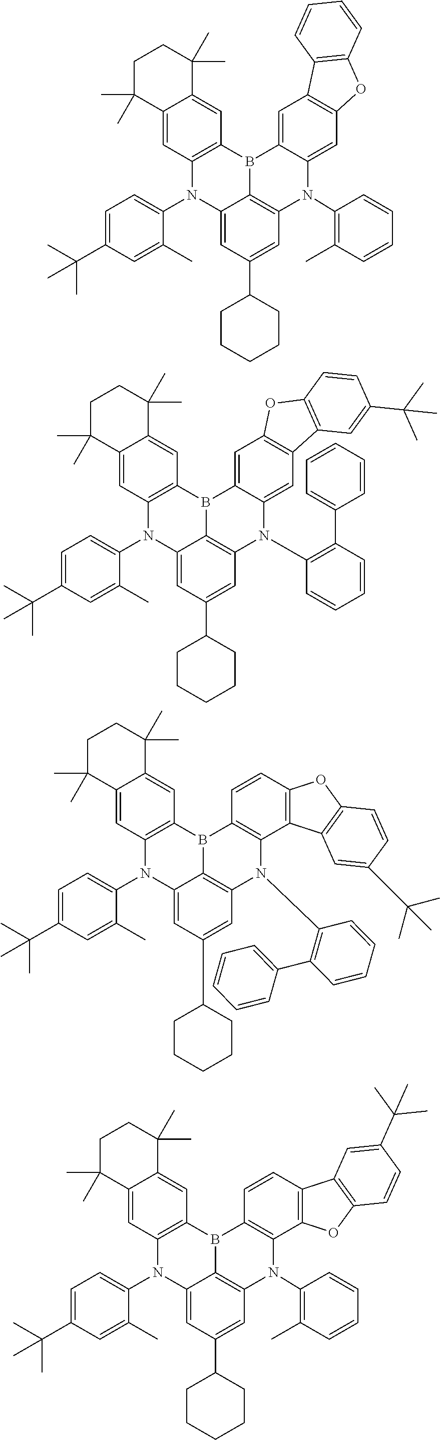

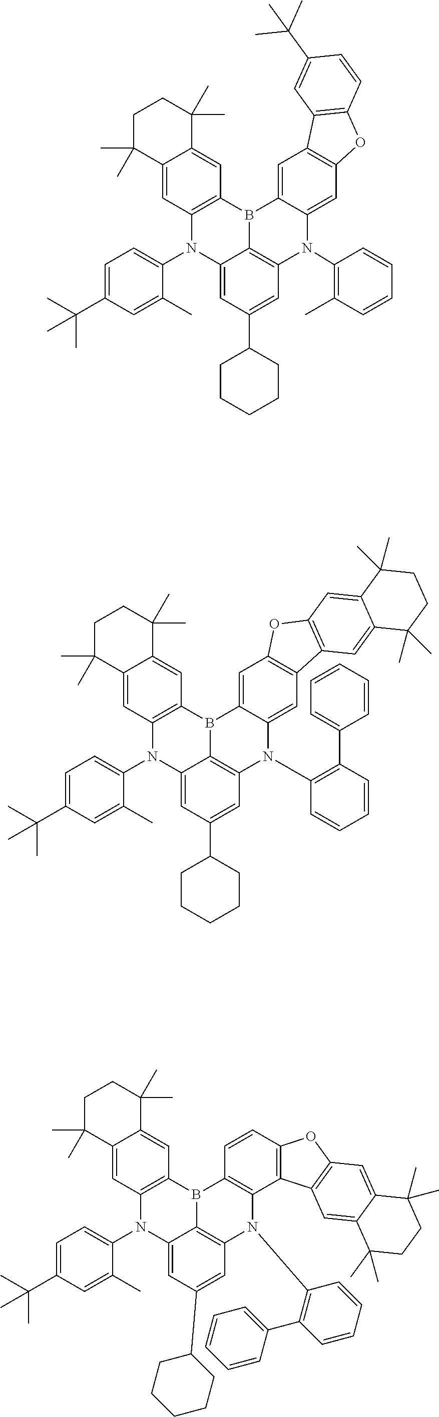

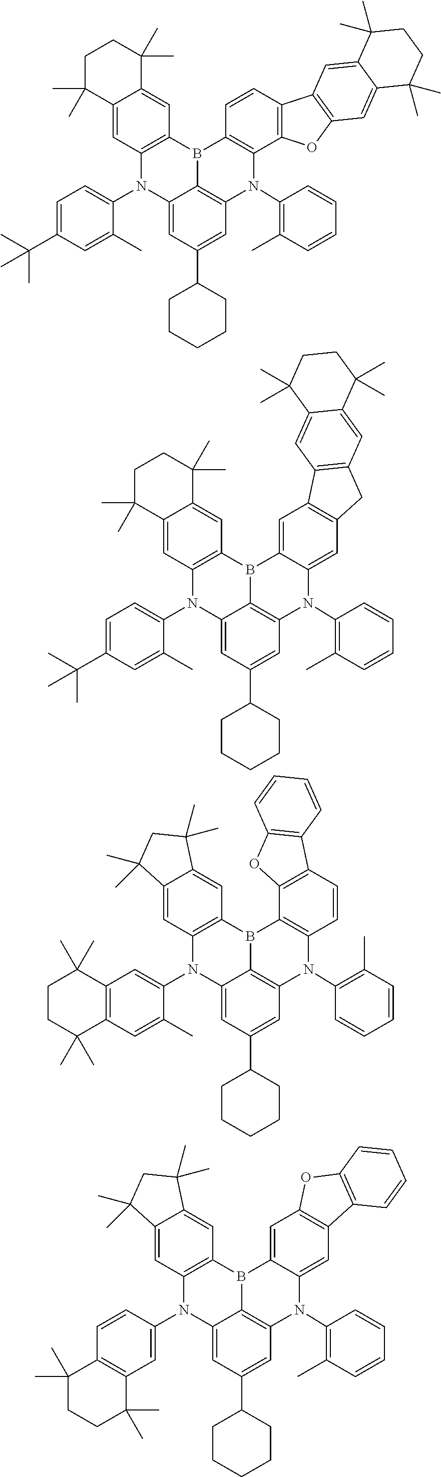

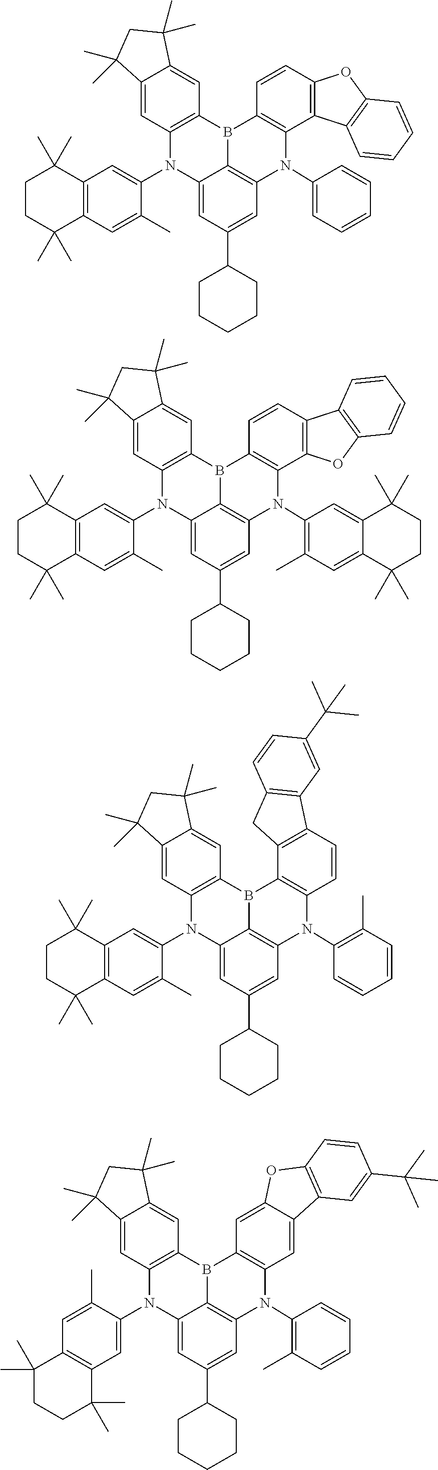

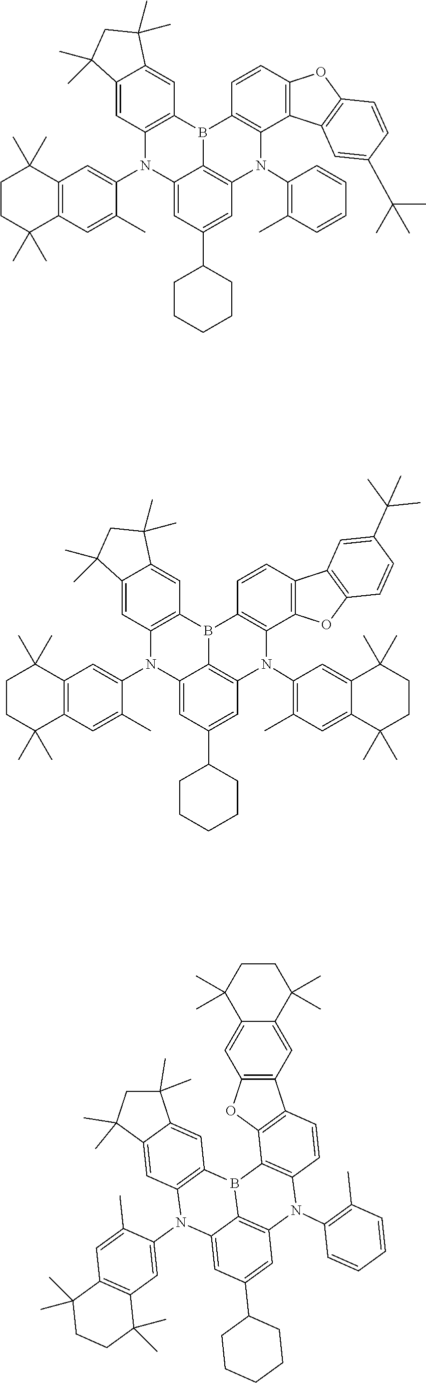

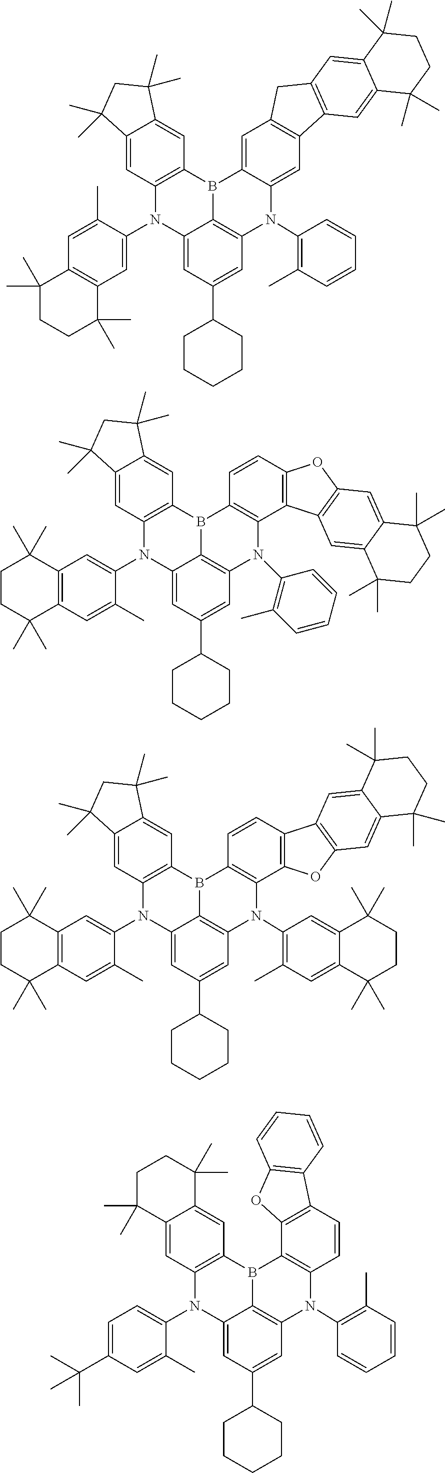

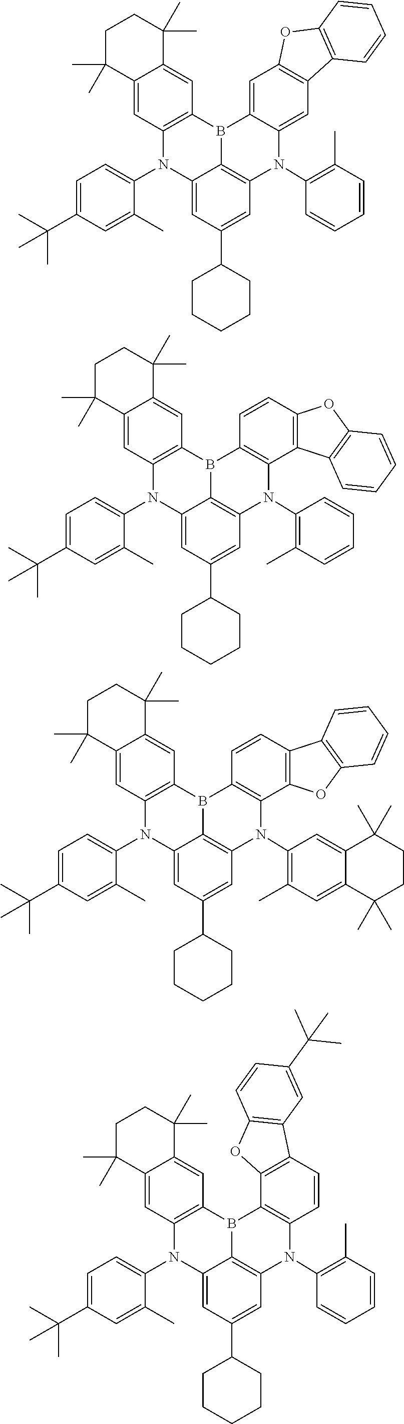

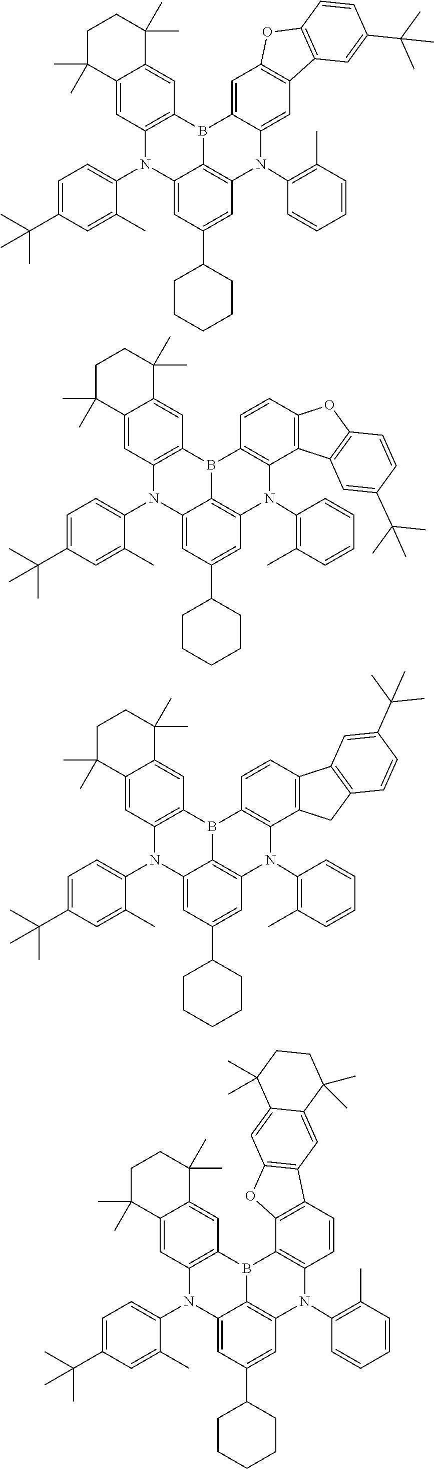

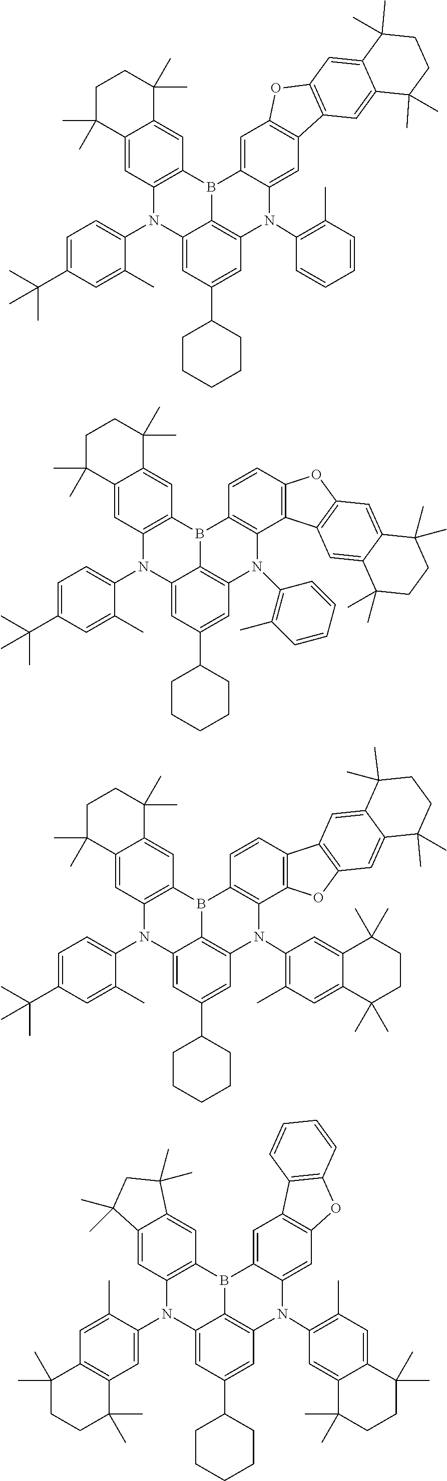

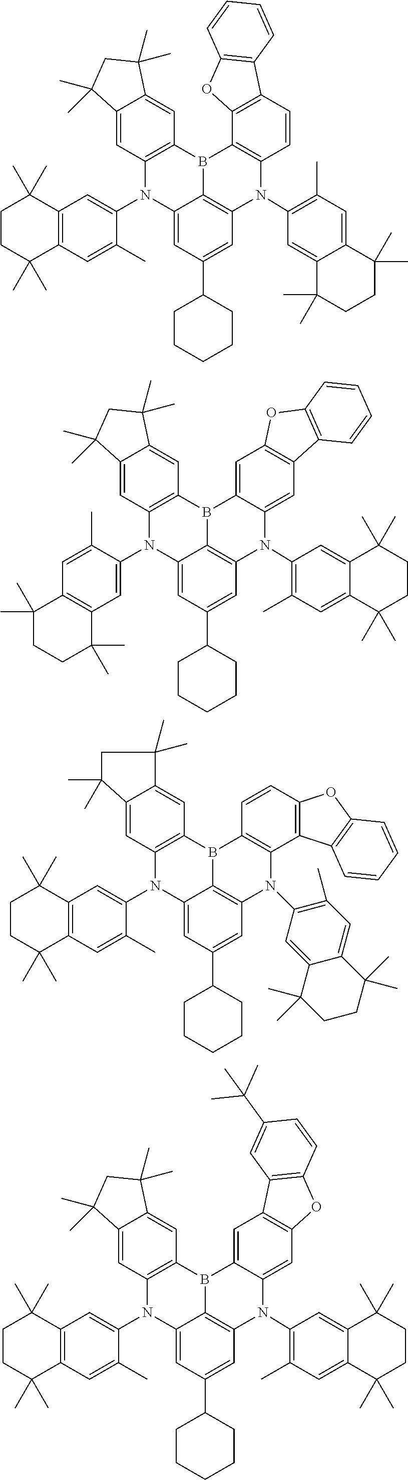

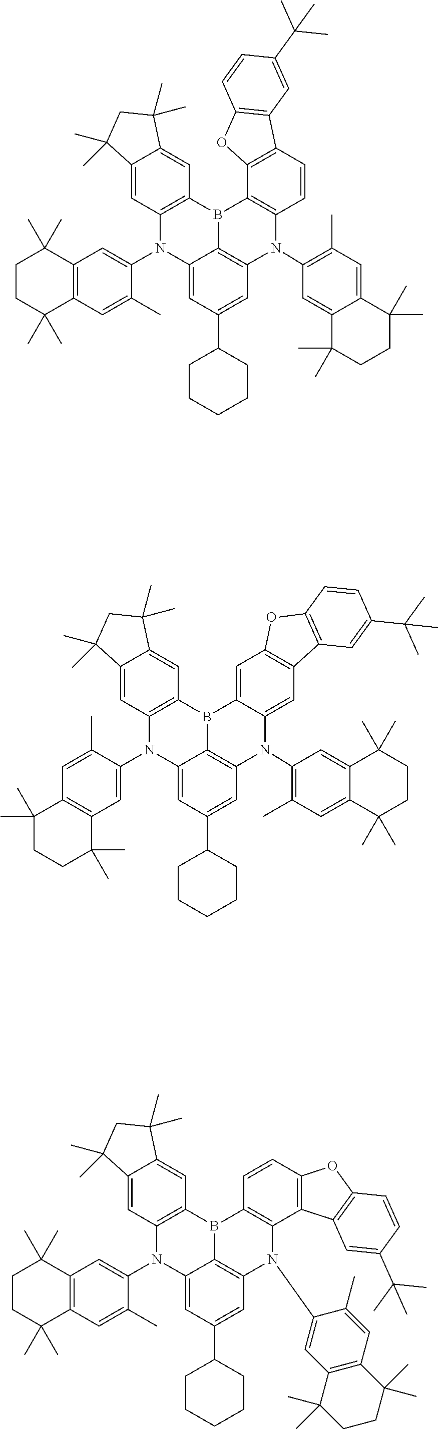

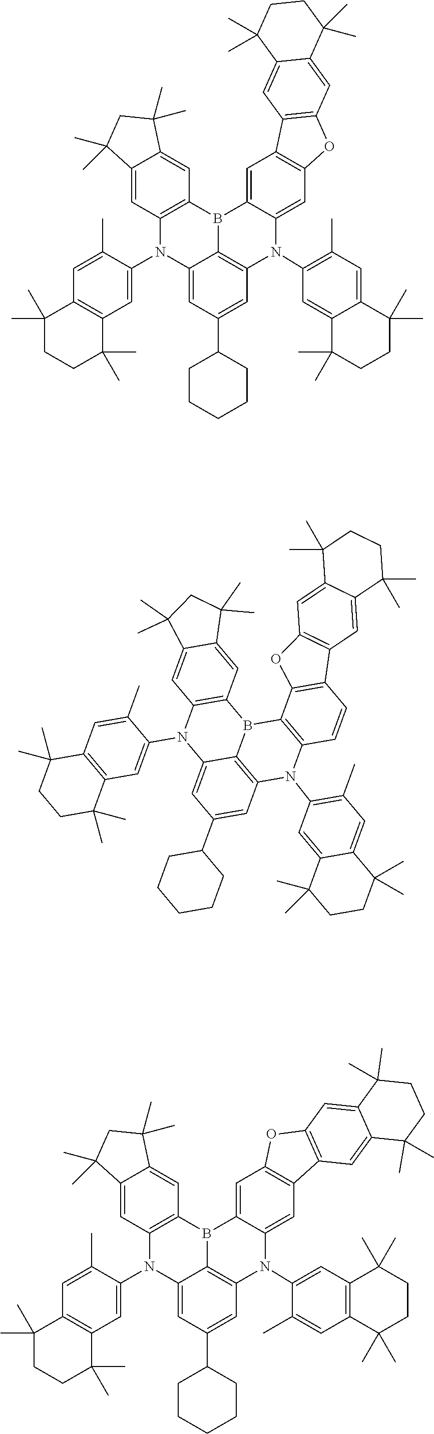

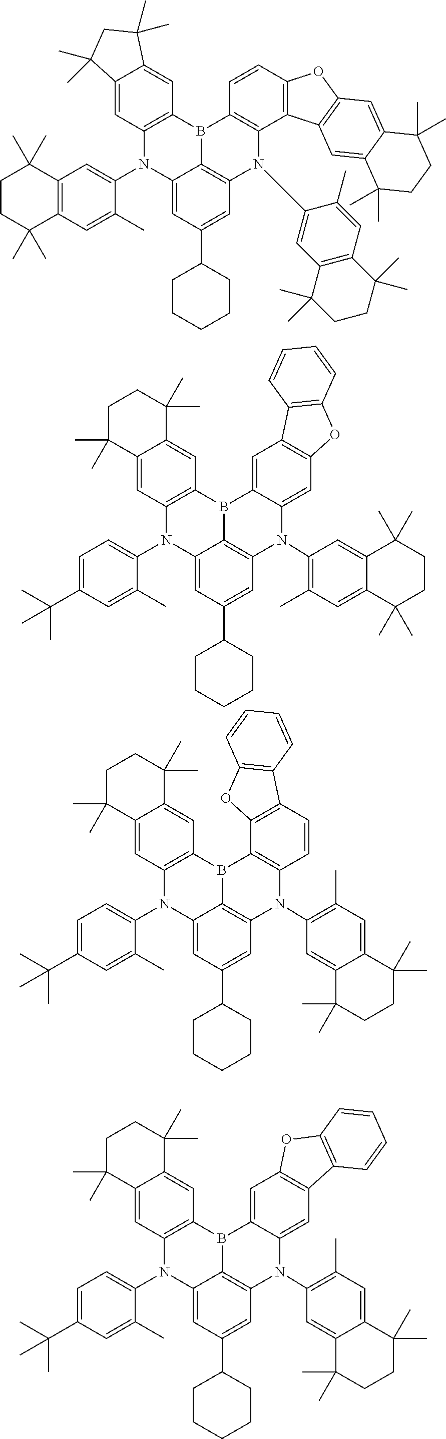

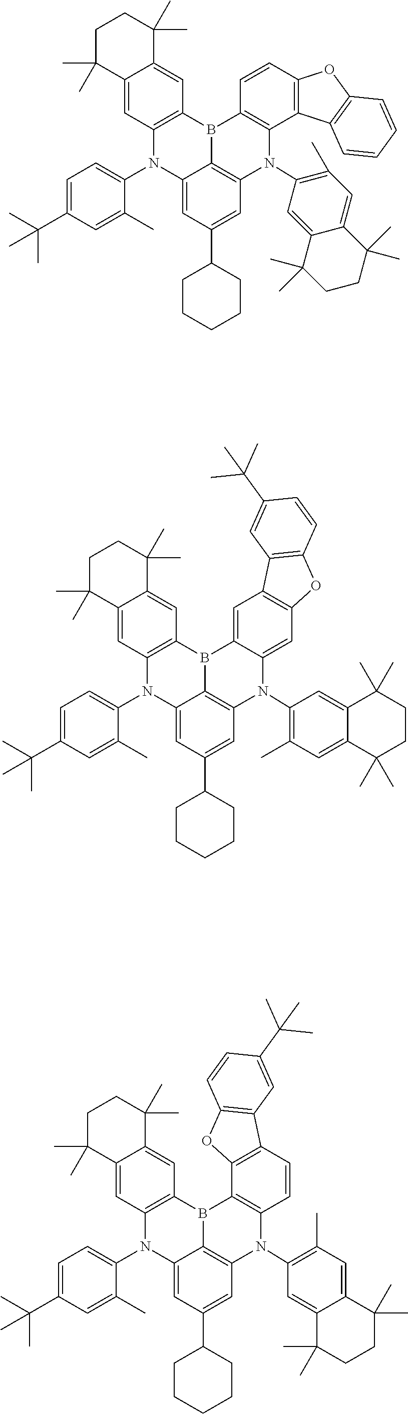

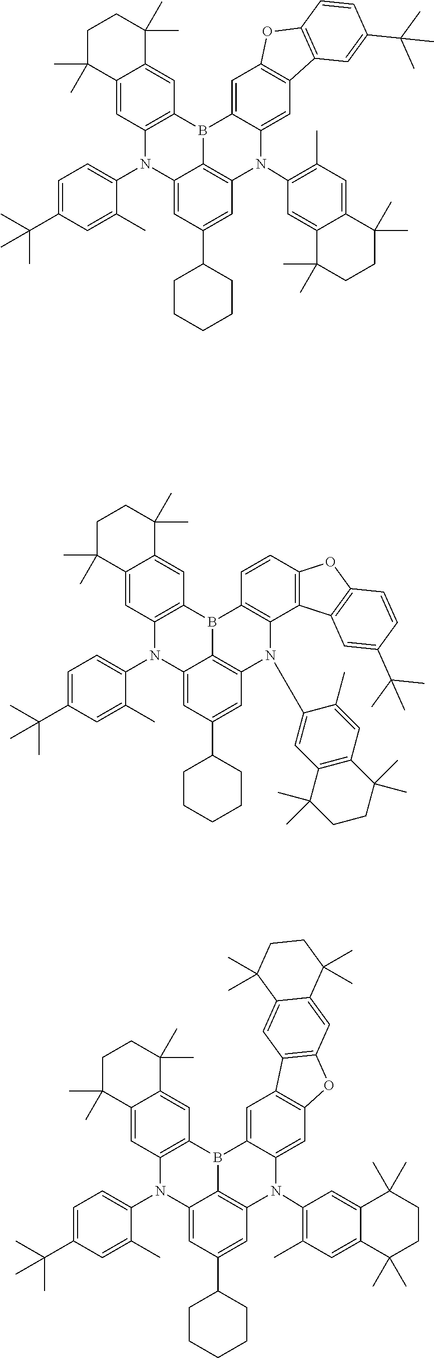

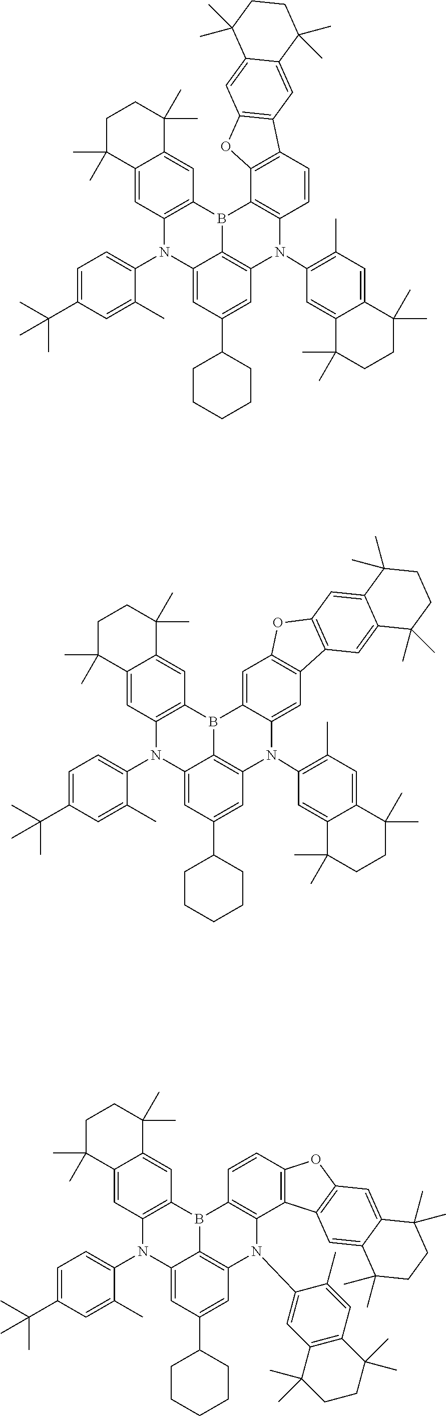

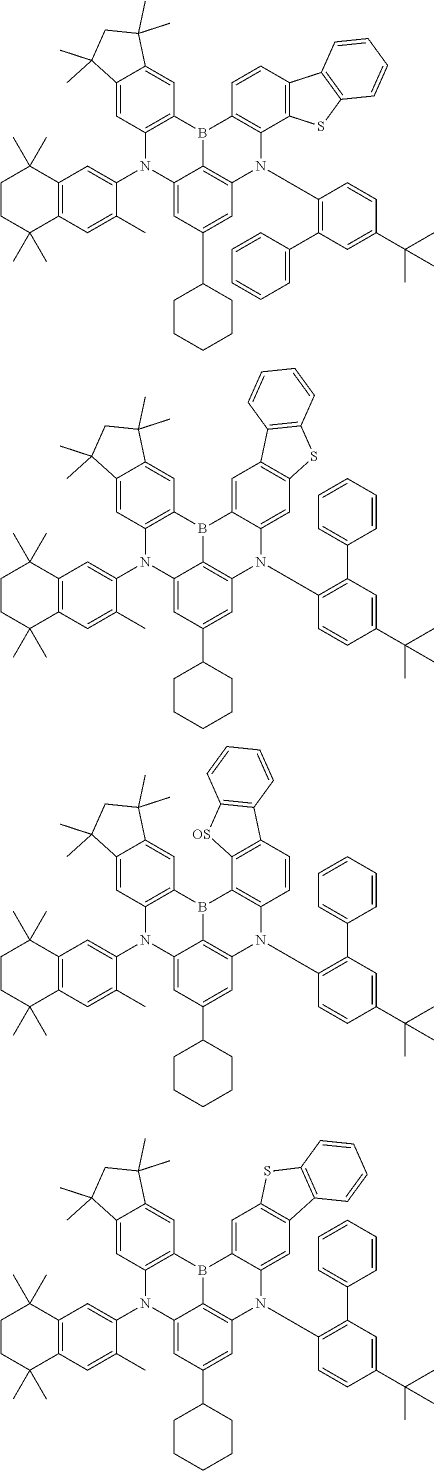

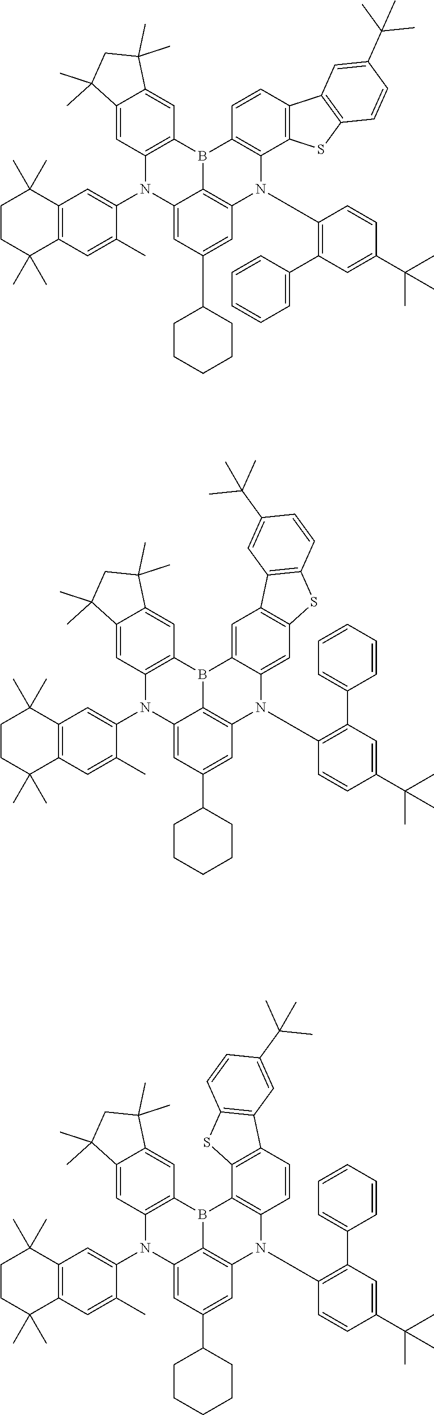 [SMILES: Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(C1CCCCC1)cc5N(c1ccc(C(C)(C)C)cc1-c1ccccc1)c1ccc5c(sc6ccc(C(C)(C)C)cc65)c13)C(C)(C)CC4(C)C)C(C)(C)CCC2(C)C]

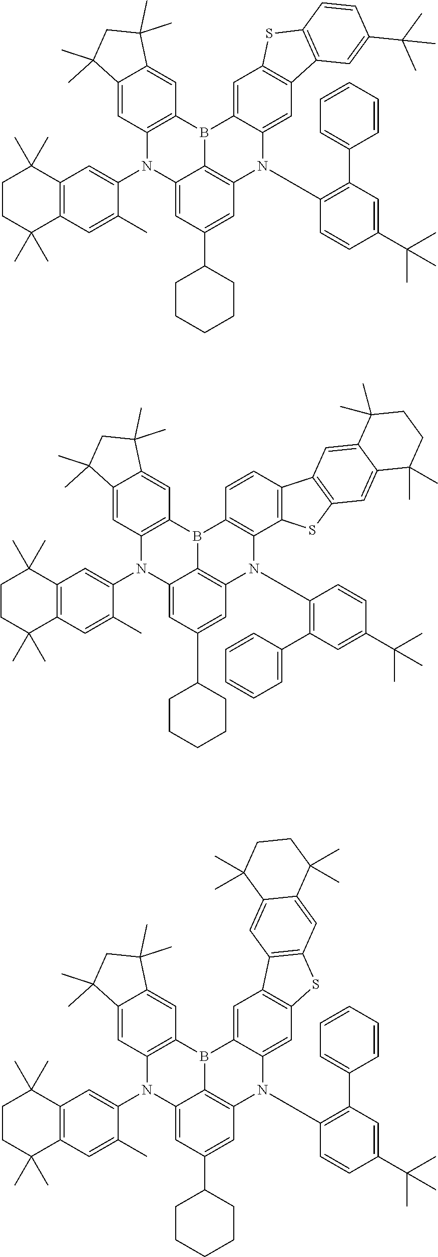 [SMILES: Cc1cc2c(cc1N1c3cc4c(cc3B3c5cc6sc7ccc(C(C)(C)C)cc7c6cc5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(C7CCCCC7)cc1c53)sc1cc3c(cc16)C(C)(C)CCC3(C)C)C(C)(C)CC4(C)C)C(C)(C)CCC2(C)C]

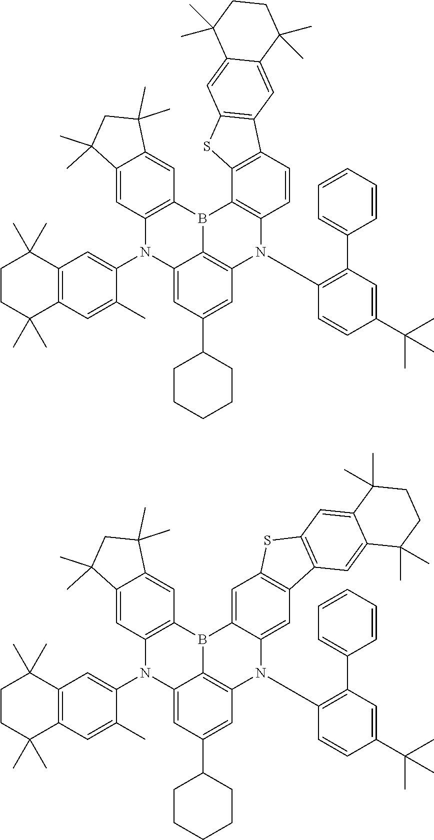 [SMILES: Cc1cc2c(cc1N1c3cc4c(cc3B3c5c1cc(C1CCCCC1)cc5N(c1ccc(C(C)(C)C)cc1-c1ccccc1)c1ccc5c(sc6cc7c(cc65)C(C)(C)CCC7(C)C)c13)C(C)(C)CC4(C)C)C(C)(C)CCC2(C)C ; Cc1cc2c(cc1N1c3cc4c(cc3B3c5cc6sc7cc8c(cc7c6cc5N(c5ccc(C(C)(C)C)cc5-c5ccccc5)c5cc(C6CCCCC6)cc1c53)C(C)(C)CCC8(C)C)C(C)(C)CC4(C)C)C(C)(C)CCC2(C)C]

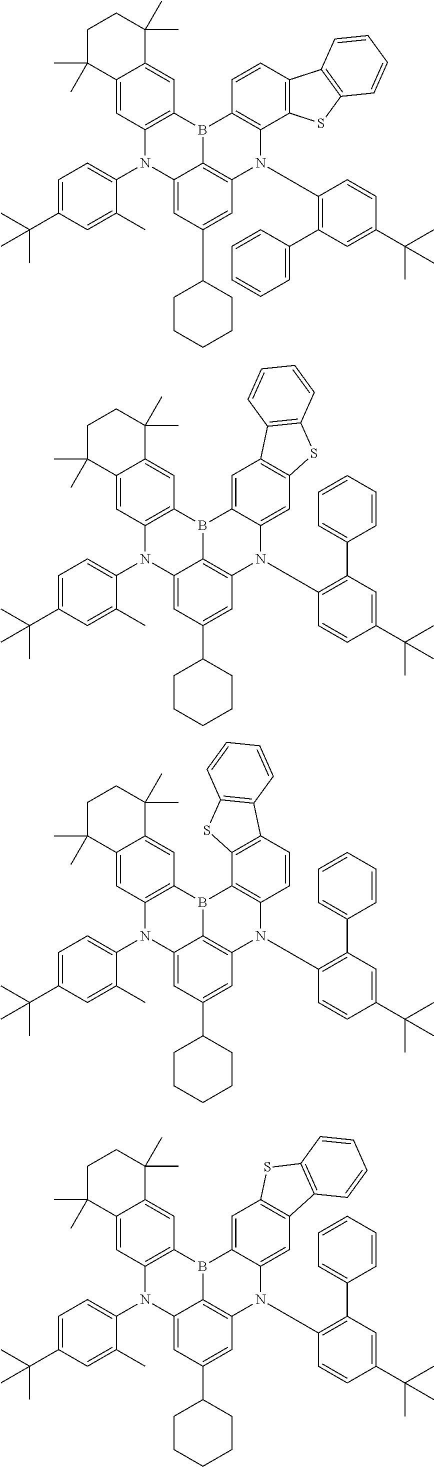

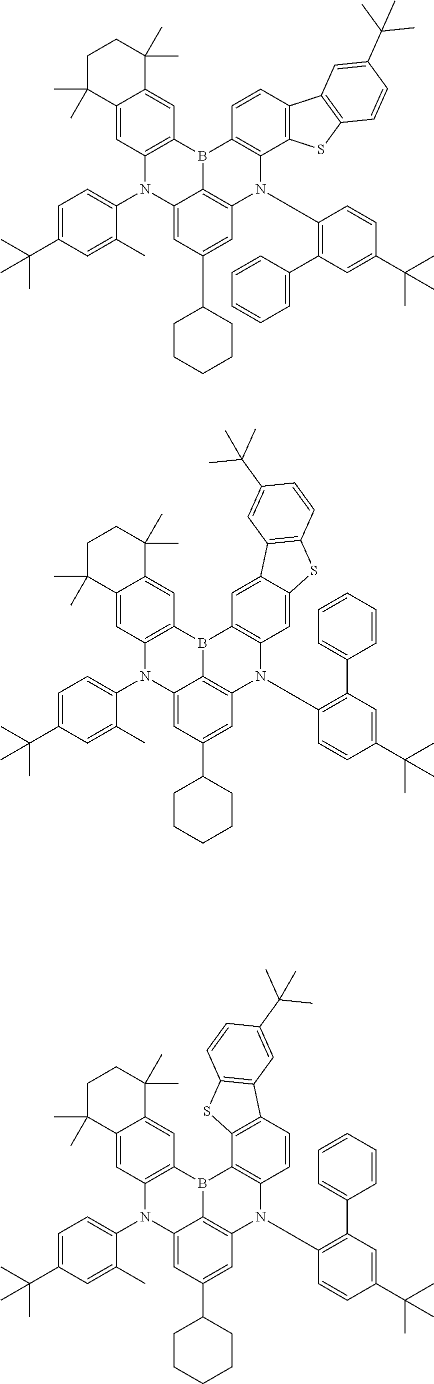

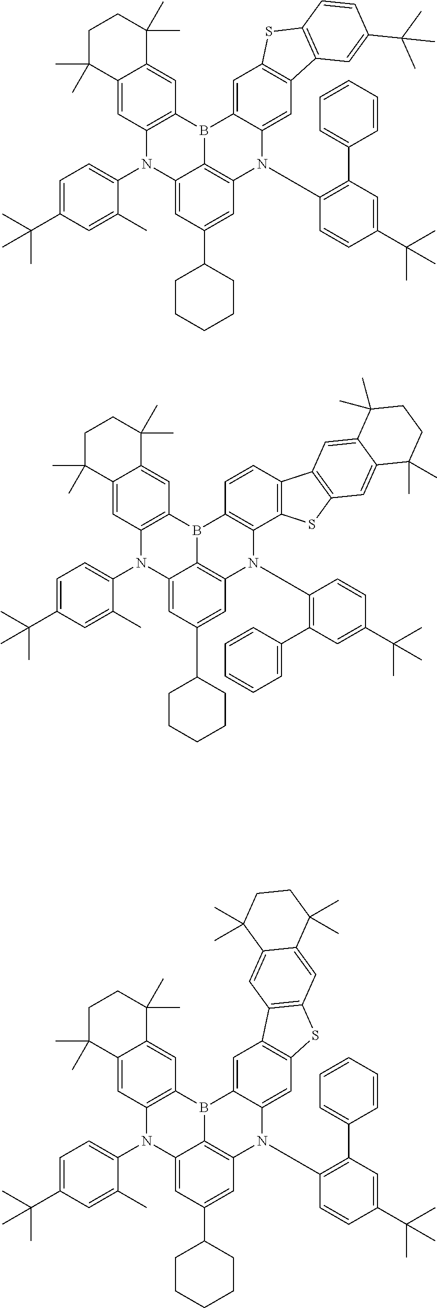

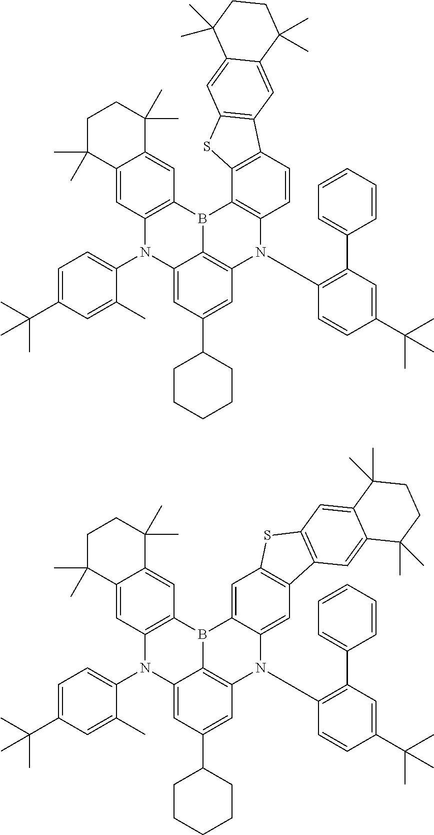

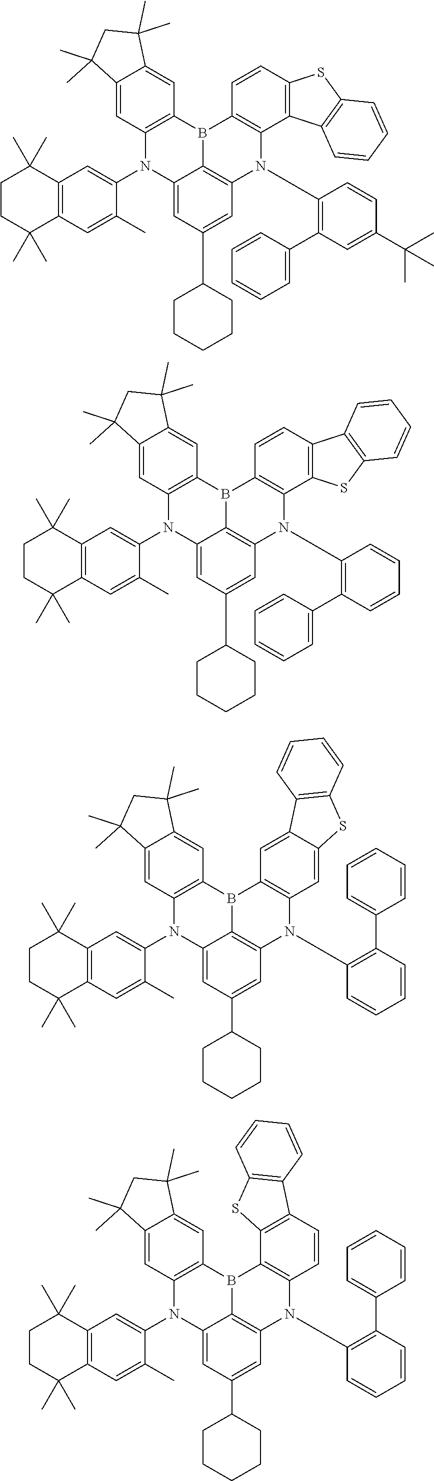

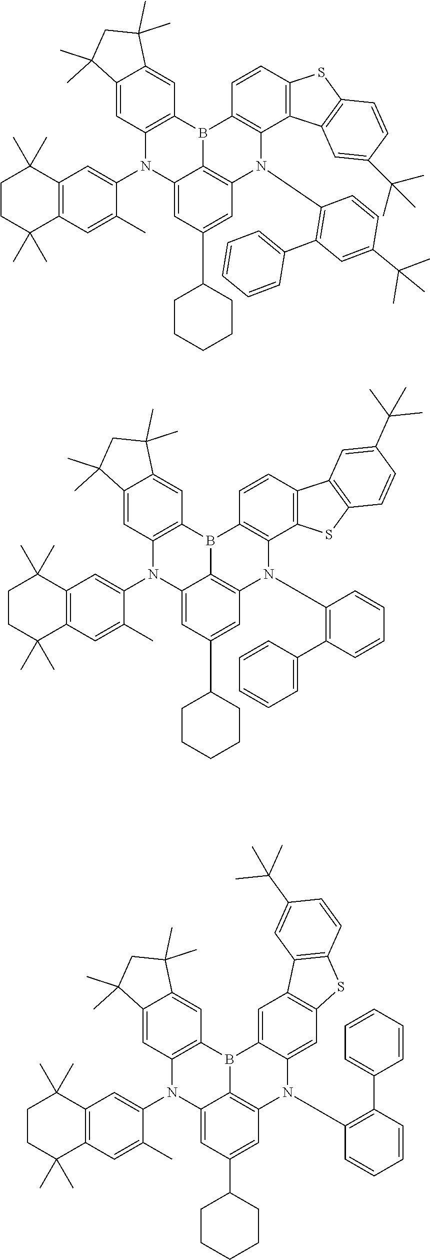 [SMILES: Cc1cc2c(cc1N1c3cc4c(cc3B3c5ccc6sc7ccc(C(C)(C)C)cc7c6c5N(c5ccc(C(C)(C)C)cc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5ccccc5-c5ccccc5)c5cc(C7CCCCC7)cc1c53)sc1ccc(C(C)(C)C)cc16)C(C)(C)CC4(C)C)C(C)(C)CCC2(C)C]

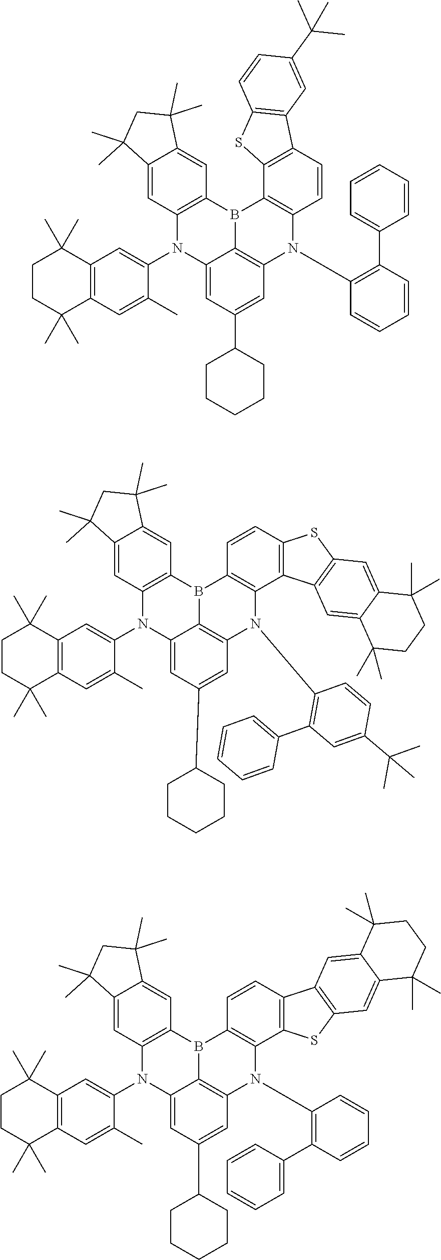 [SMILES: Cc1cc2c(cc1N1c3cc4c(cc3B3c5c1cc(C1CCCCC1)cc5N(c1ccccc1-c1ccccc1)c1ccc5c(sc6ccc(C(C)(C)C)cc65)c13)C(C)(C)CC4(C)C)C(C)(C)CCC2(C)C ; Cc1cc2c(cc1N1c3cc4c(cc3B3c5ccc6sc7cc8c(cc7c6c5N(c5ccc(C(C)(C)C)cc5-c5ccccc5)c5cc(C6CCCCC6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5-c5ccccc5)c5cc(C6CCCCC6)cc1c53)C(C)(C)CC4(C)C)C(C)(C)CCC2(C)C]

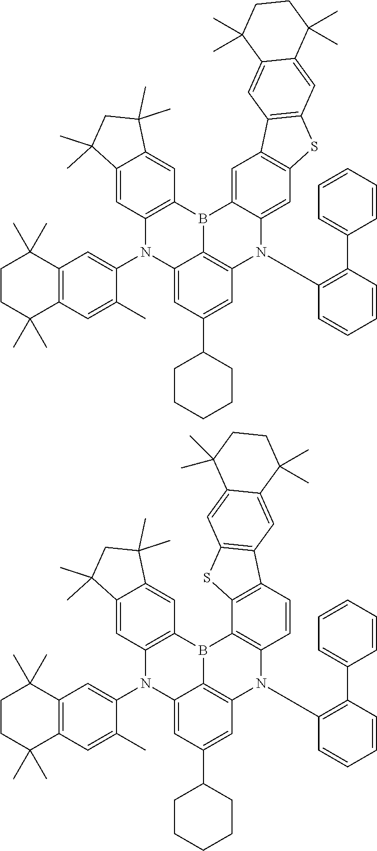

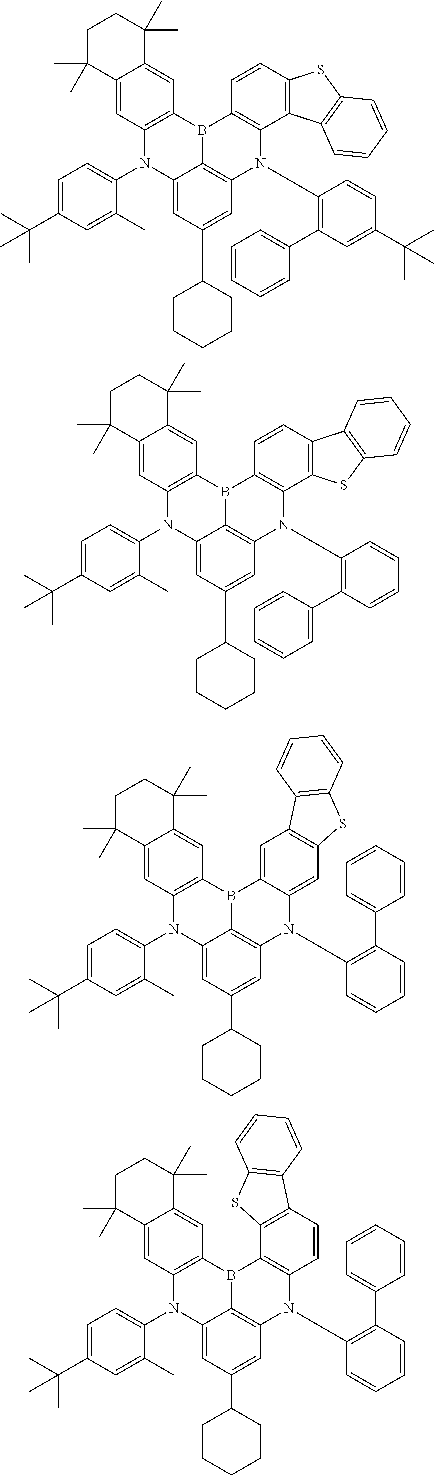

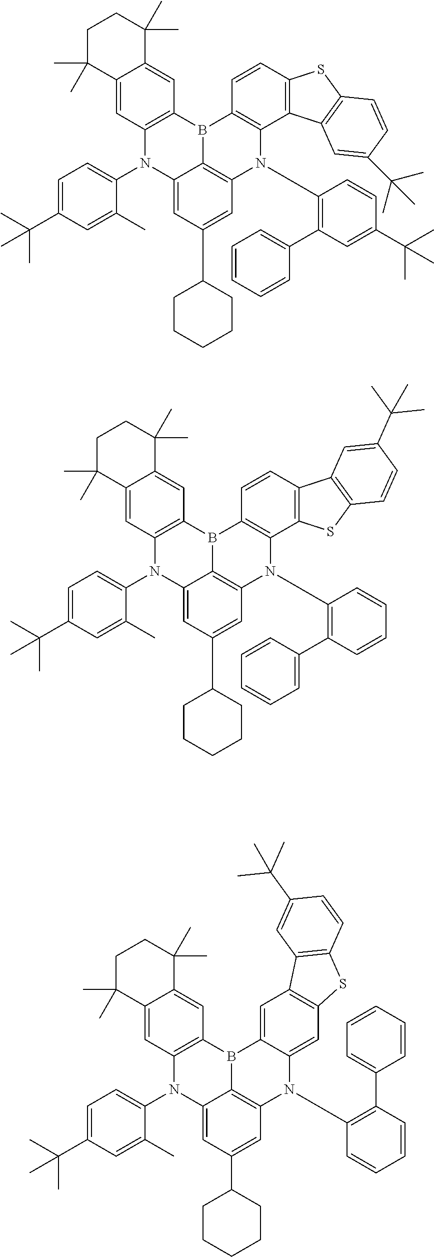

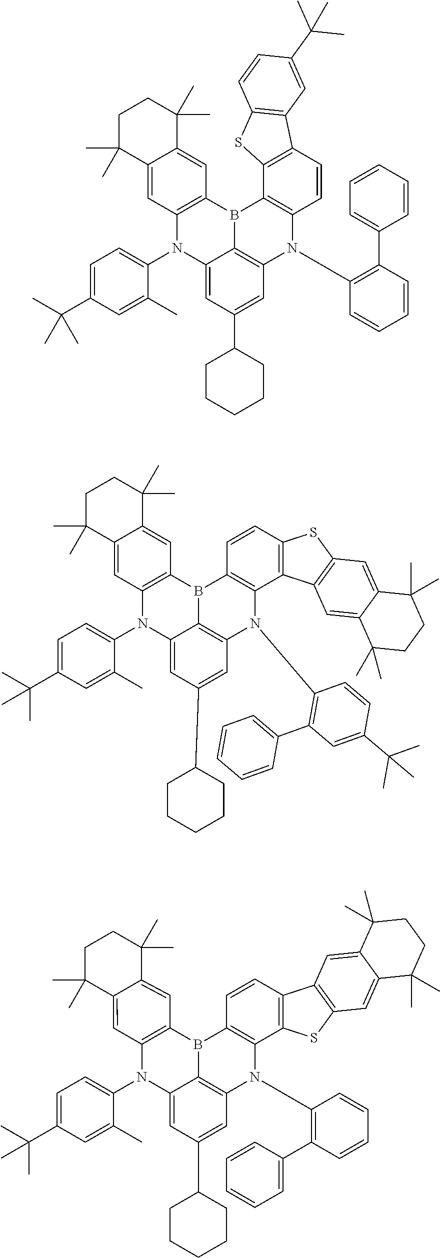

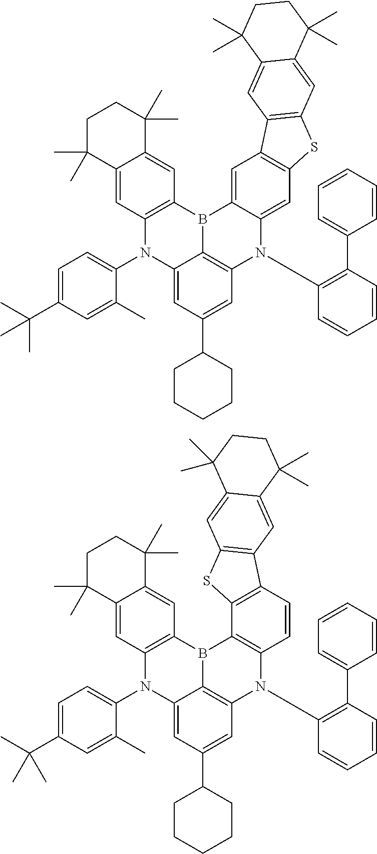

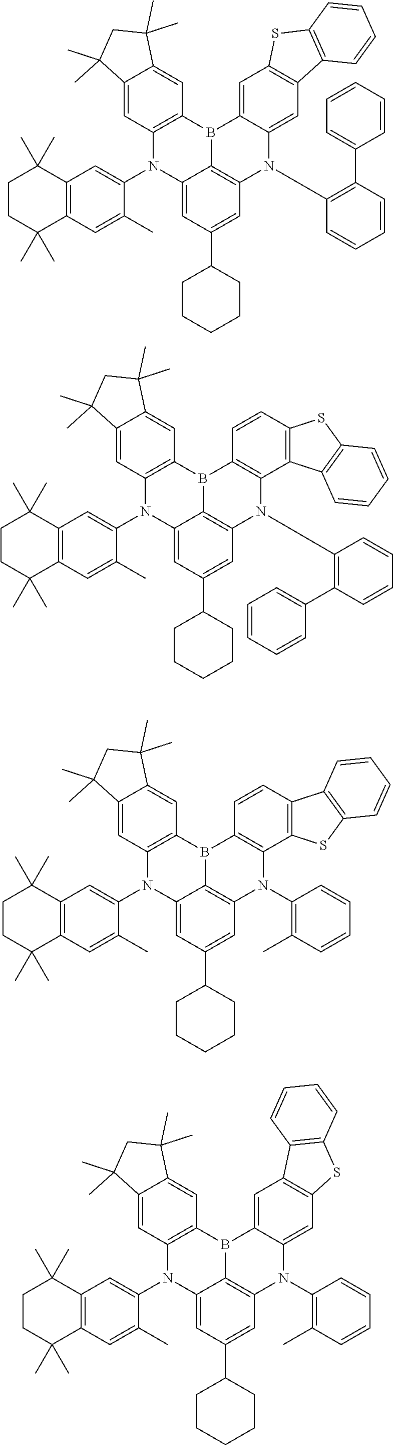 [SMILES: Cc1cc2c(cc1N1c3cc4c(cc3B3c5cc6sc7ccccc7c6cc5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6sc7ccccc7c6c5N(c5ccccc5-c5ccccc5)c5cc(C6CCCCC6)cc1c53)C(C)(C)CC4(C)C)C(C)(C)CCC2(C)C ; Cc1cc2c(cc1N1c3cc4c(cc3B3c5ccc6c(sc7ccccc76)c5N(c5ccccc5C)c5cc(C6CCCCC6)cc1c53)C(C)(C)CC4(C)C)C(C)(C)CCC2(C)C ; Cc1ccccc1N1c2cc3sc4ccccc4c3cc2B2c3cc4c(cc3N(c3cc5c(cc3C)C(C)(C)CCC5(C)C)c3cc(C5CCCCC5)cc1c32)C(C)(C)CC4(C)C]

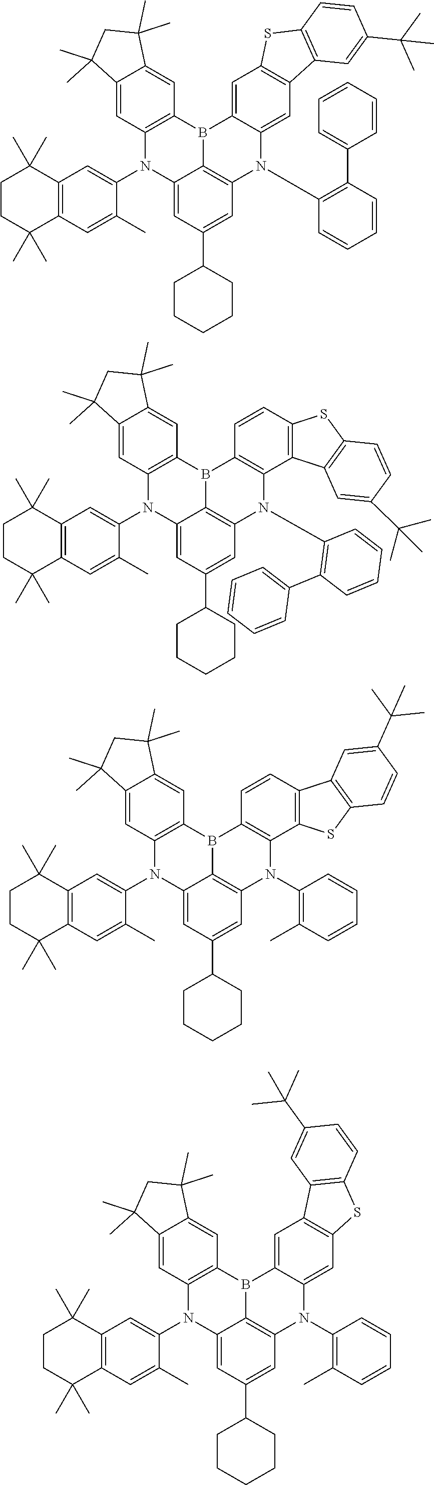

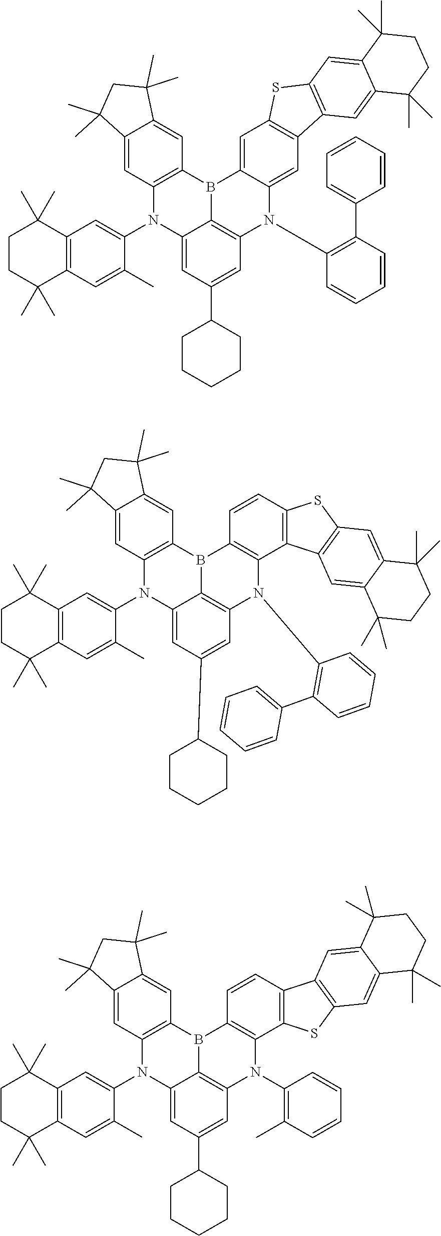 [SMILES: Cc1cc2c(cc1N1c3cc4c(cc3B3c5cc6sc7cc8c(cc7c6cc5N(c5ccccc5-c5ccccc5)c5cc(C6CCCCC6)cc1c53)C(C)(C)CCC8(C)C)C(C)(C)CC4(C)C)C(C)(C)CCC2(C)C ; Cc1cc2c(cc1N1c3cc4c(cc3B3c5ccc6sc7cc8c(cc7c6c5N(c5ccccc5-c5ccccc5)c5cc(C6CCCCC6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(C6CCCCC6)cc1c53)C(C)(C)CC4(C)C)C(C)(C)CCC2(C)C]

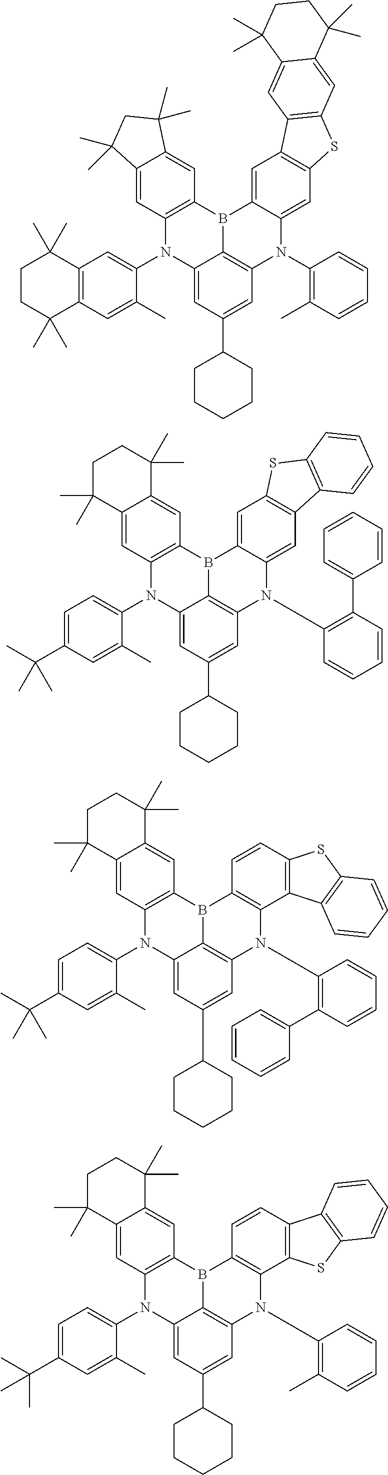

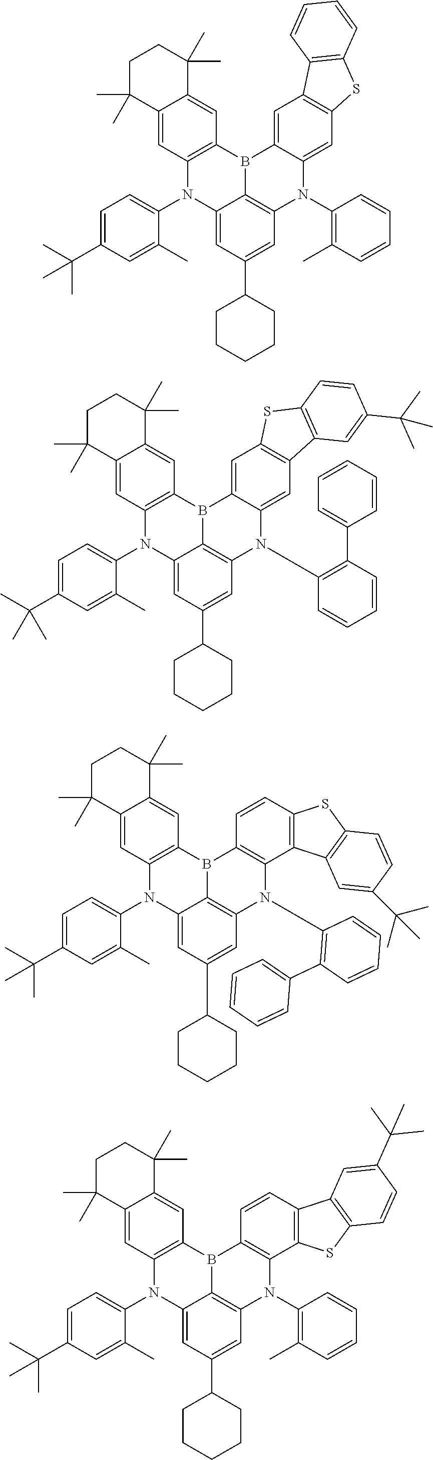

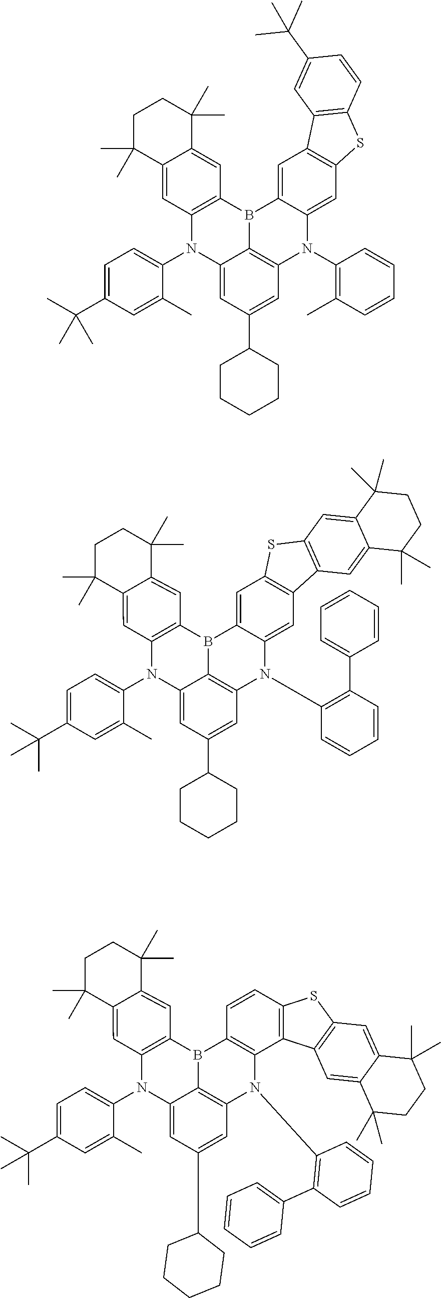

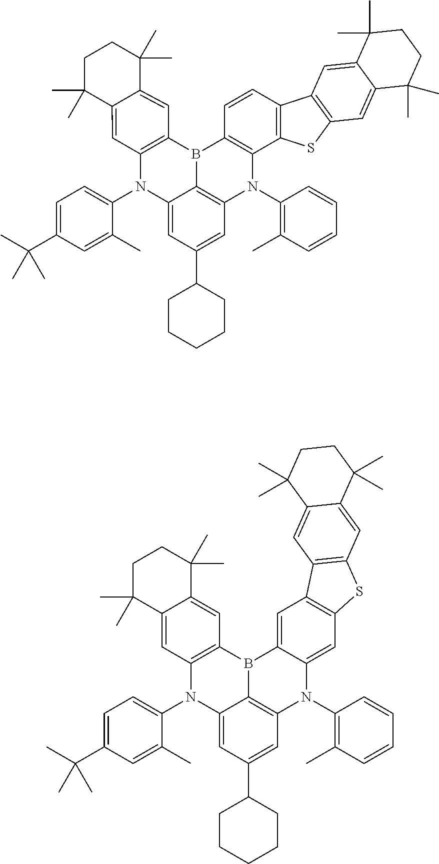

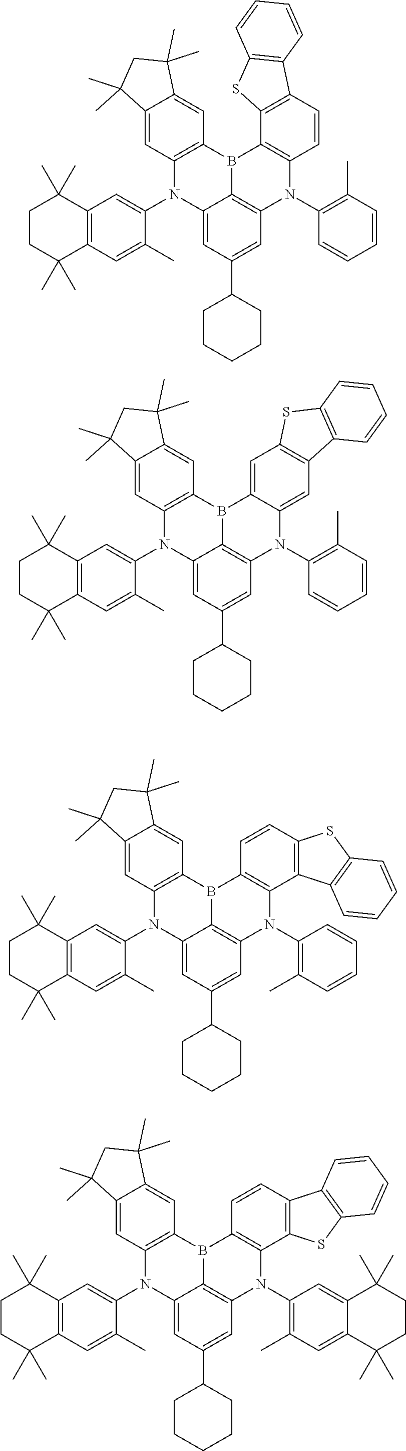

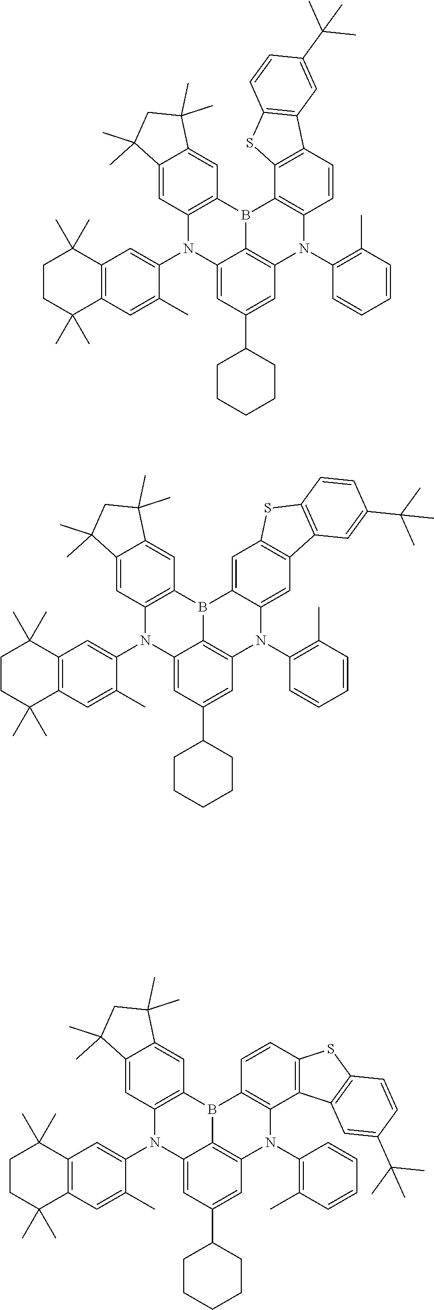 [SMILES: Cc1cc2c(cc1N1c3cc4c(cc3B3c5c1cc(C1CCCCC1)cc5N(c1ccccc1C)c1ccc5c(sc6ccc(C(C)(C)C)cc65)c13)C(C)(C)CC4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(C6CCCCC6)cc1c42)C(C)(C)CC5(C)C)sc1ccc(C(C)(C)C)cc13 ; Cc1cc2c(cc1N1c3cc4c(cc3B3c5ccc6sc7ccc(C(C)(C)C)cc7c6c5N(c5ccccc5C)c5cc(C6CCCCC6)cc1c53)C(C)(C)CC4(C)C)C(C)(C)CCC2(C)C]

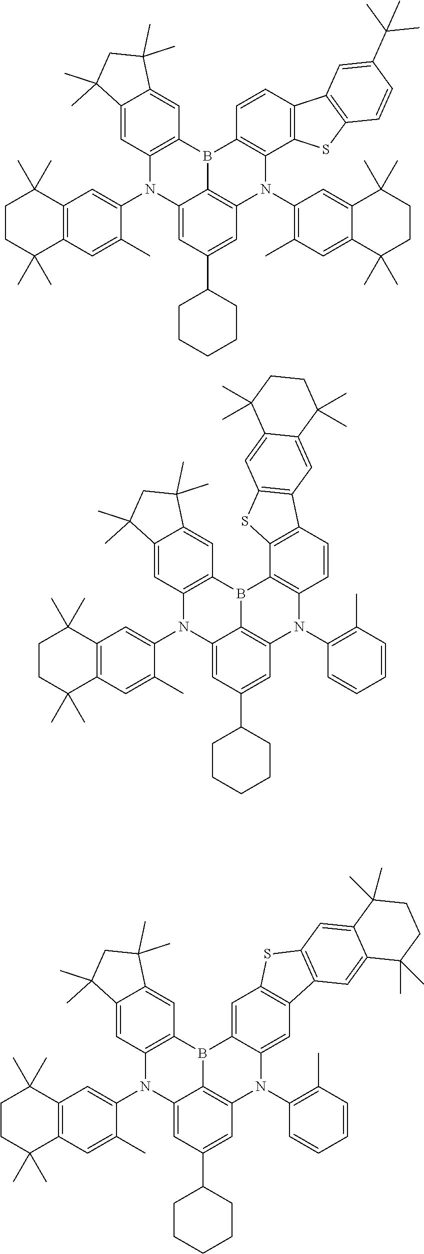

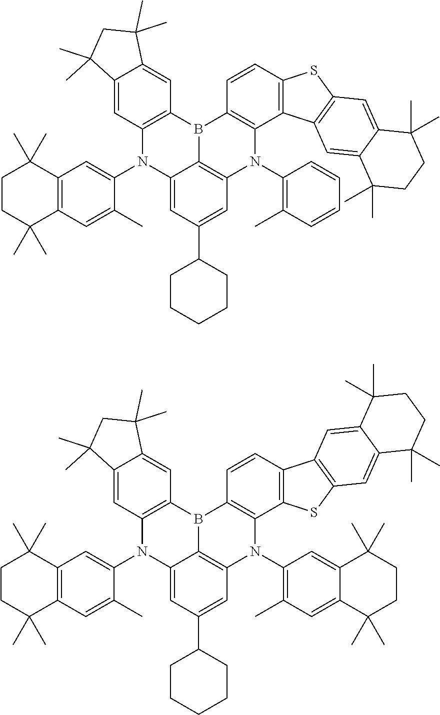

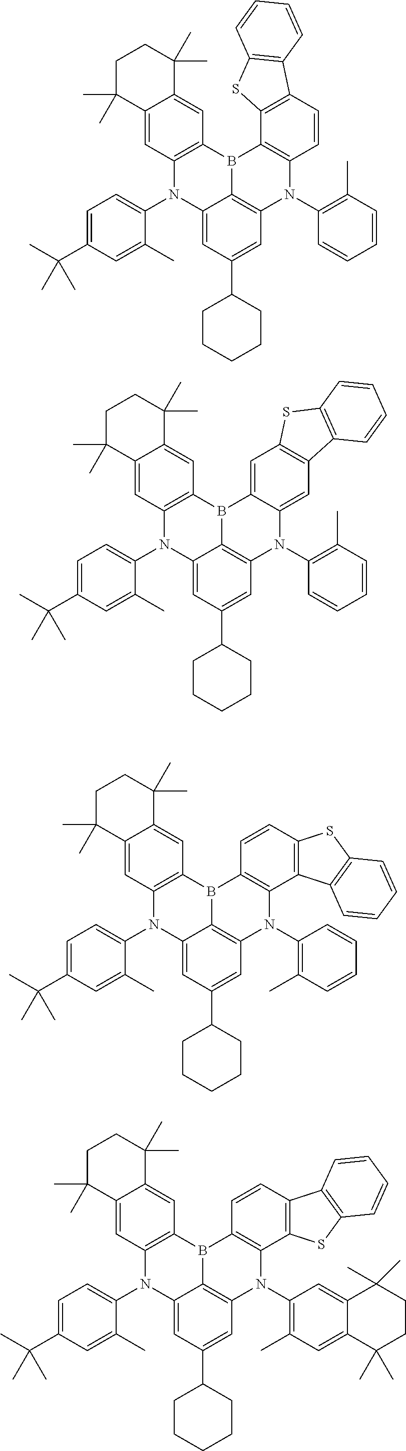

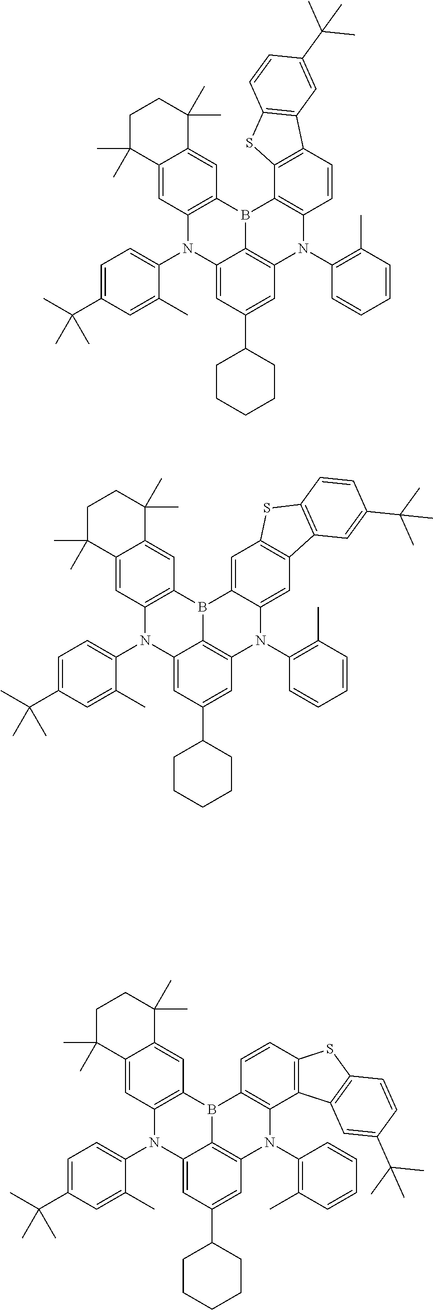

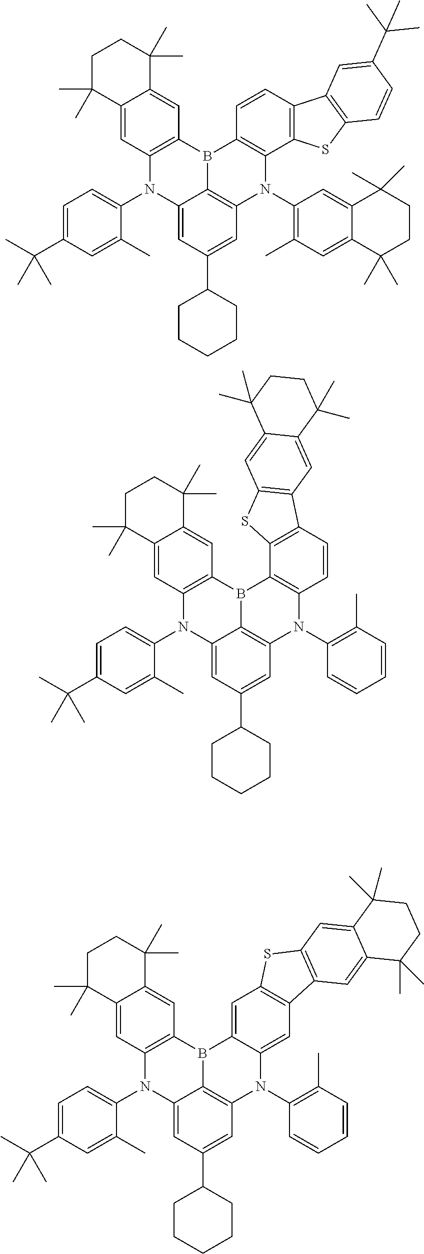

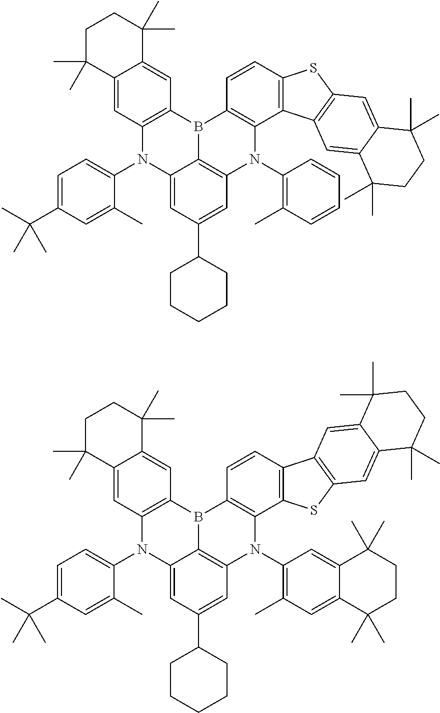

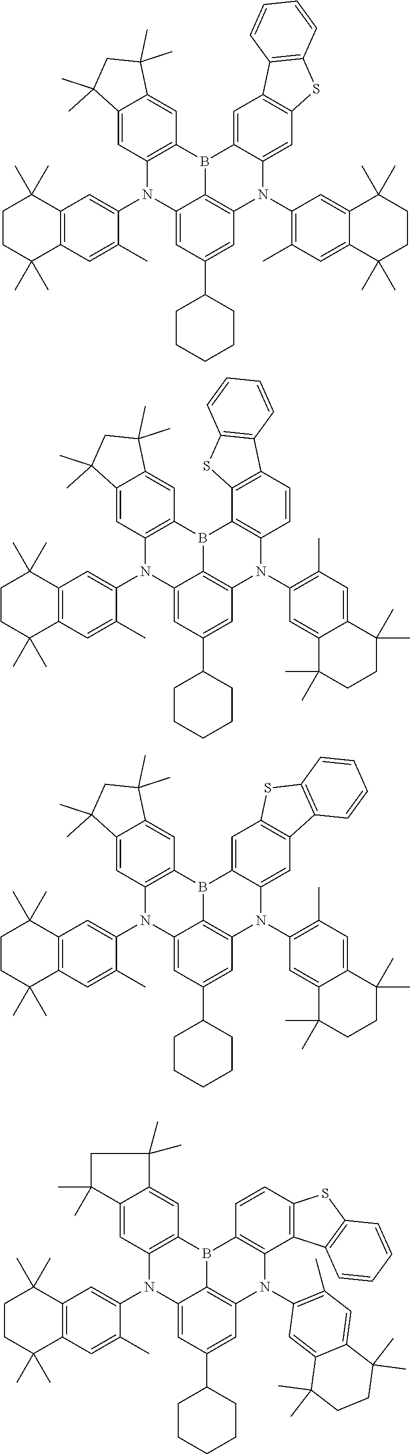

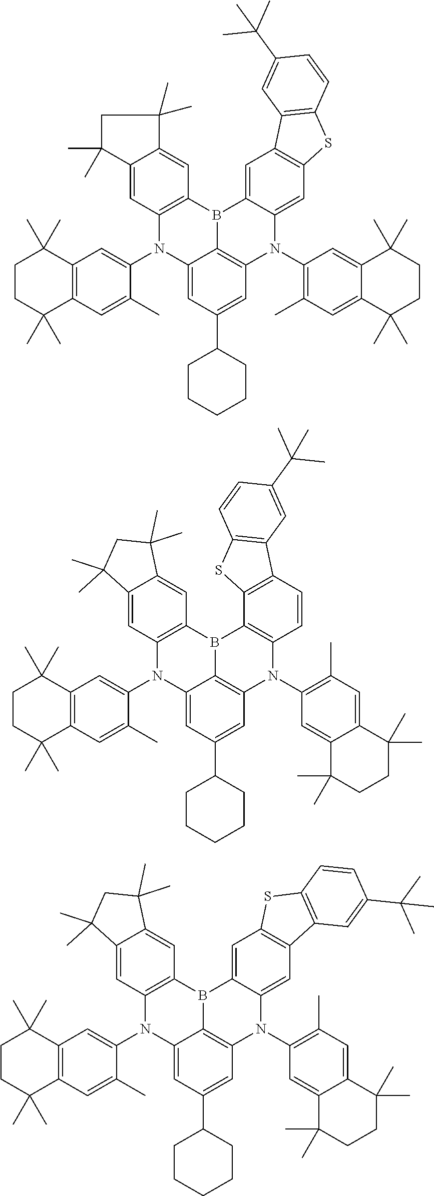

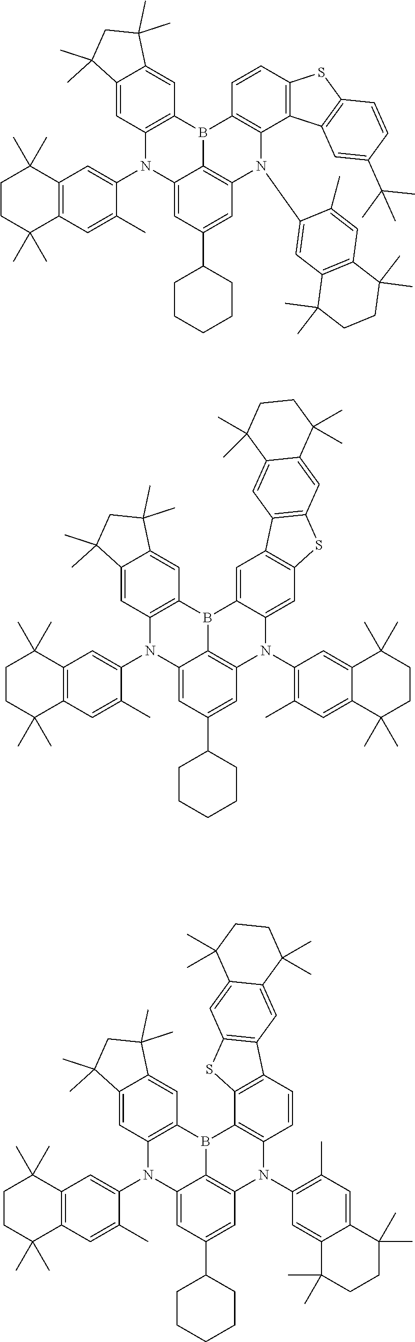 [SMILES: Cc1cc2c(cc1N1c3cc4c(cc3B3c5ccc6sc7ccc(C(C)(C)C)cc7c6c5N(c5cc6c(cc5C)C(C)(C)CCC6(C)C)c5cc(C6CCCCC6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(C7CCCCC7)cc1c53)sc1cc3c(cc16)C(C)(C)CCC3(C)C)C(C)(C)CC4(C)C)C(C)(C)CCC2(C)C ; Cc1cc2c(cc1N1c3cc4c(cc3B3c5c1cc(C1CCCCC1)cc5N(c1cc5c(cc1C)C(C)(C)CCC5(C)C)c1ccc5c(sc6cc7c(cc65)C(C)(C)CCC7(C)C)c13)C(C)(C)CC4(C)C)C(C)(C)CCC2(C)C]

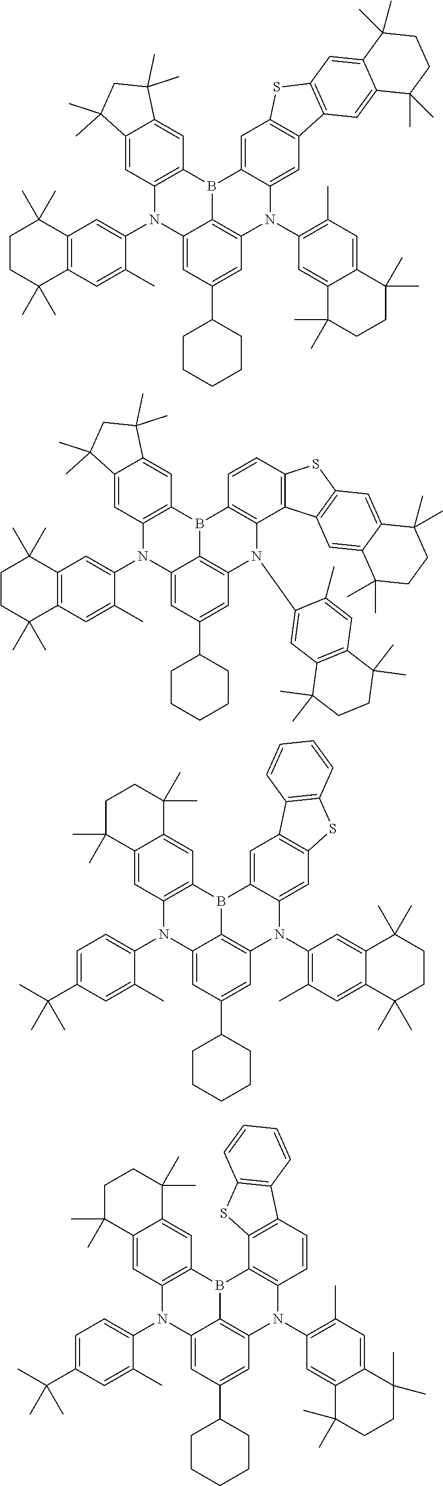

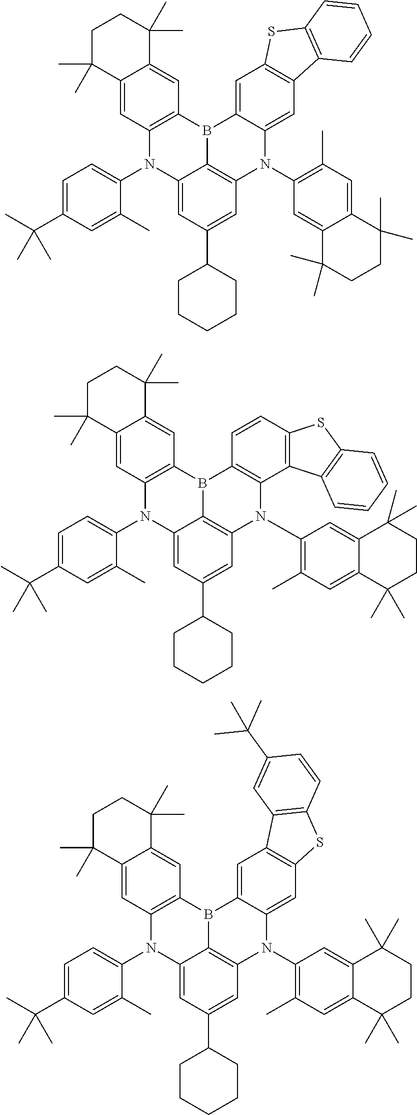

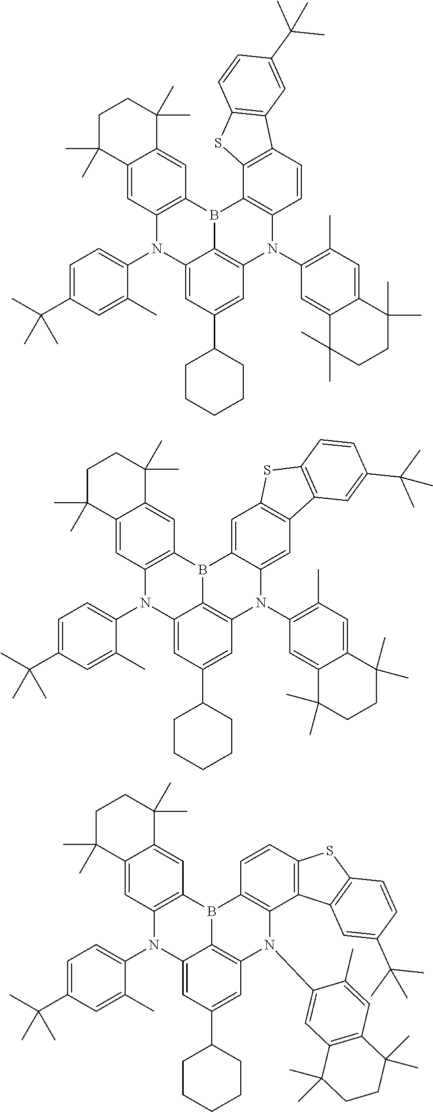

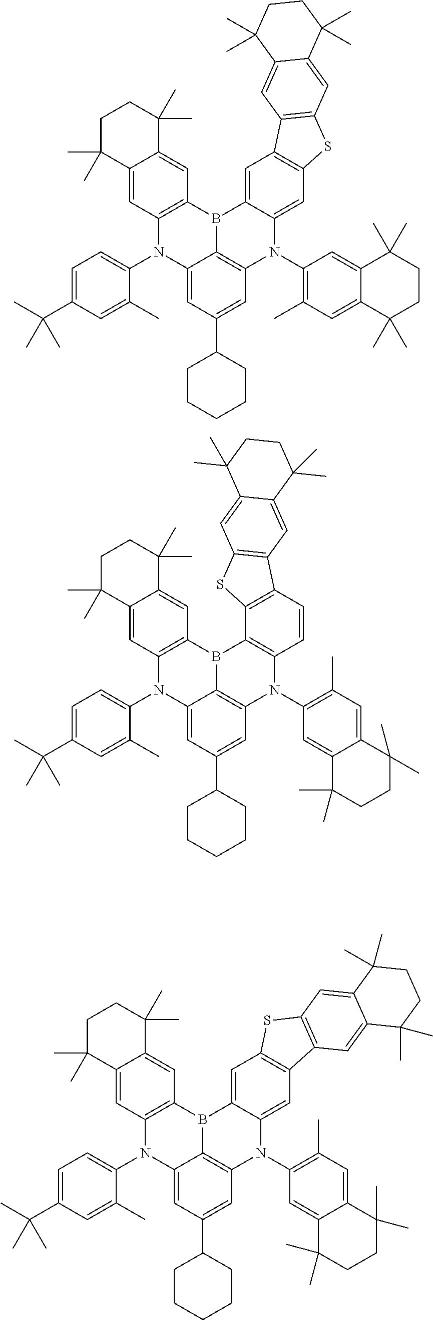

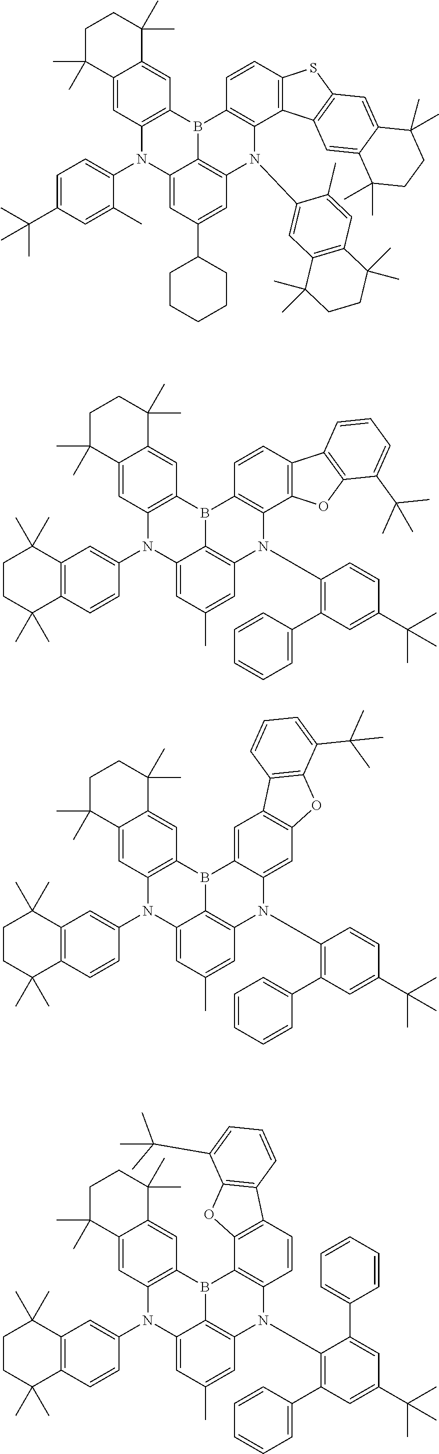

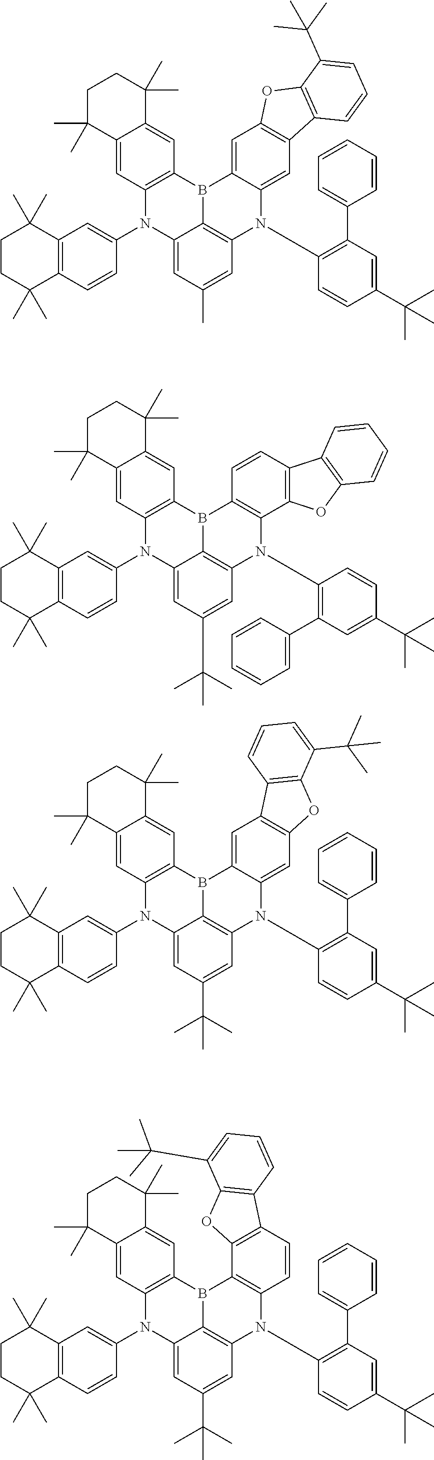

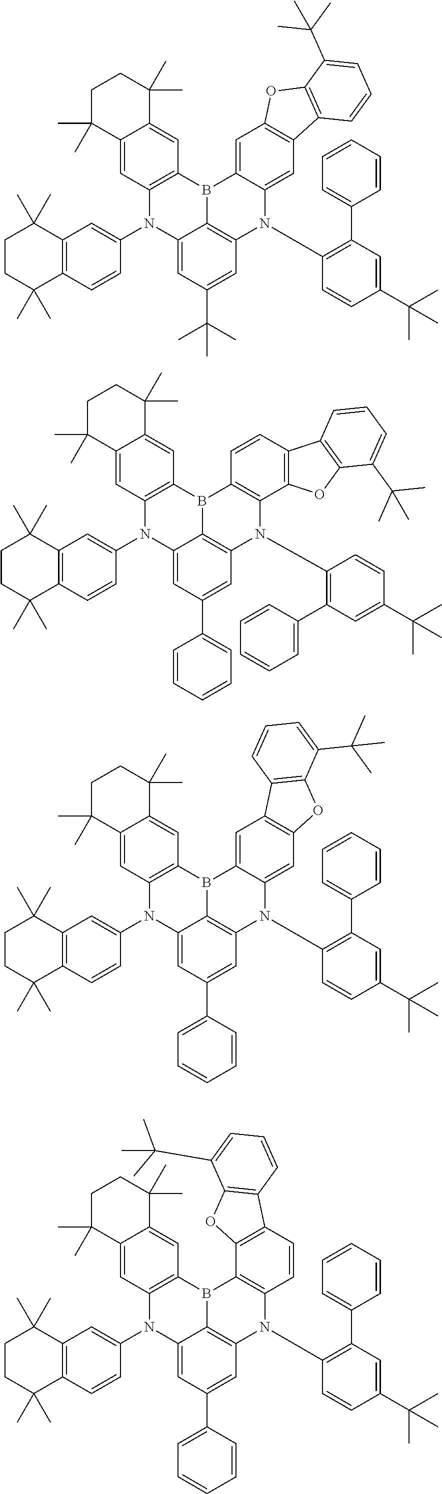

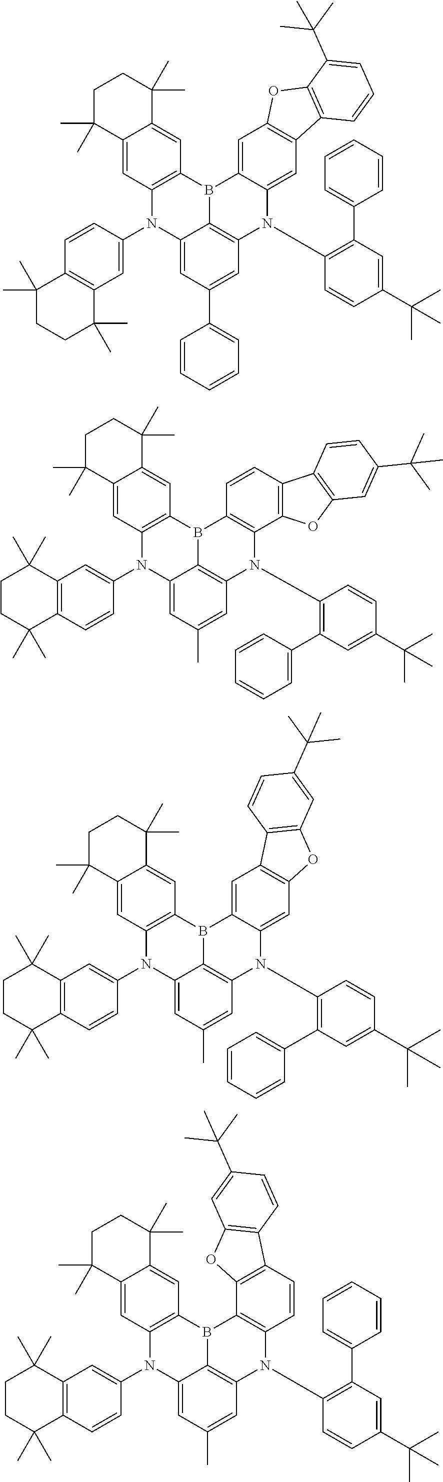

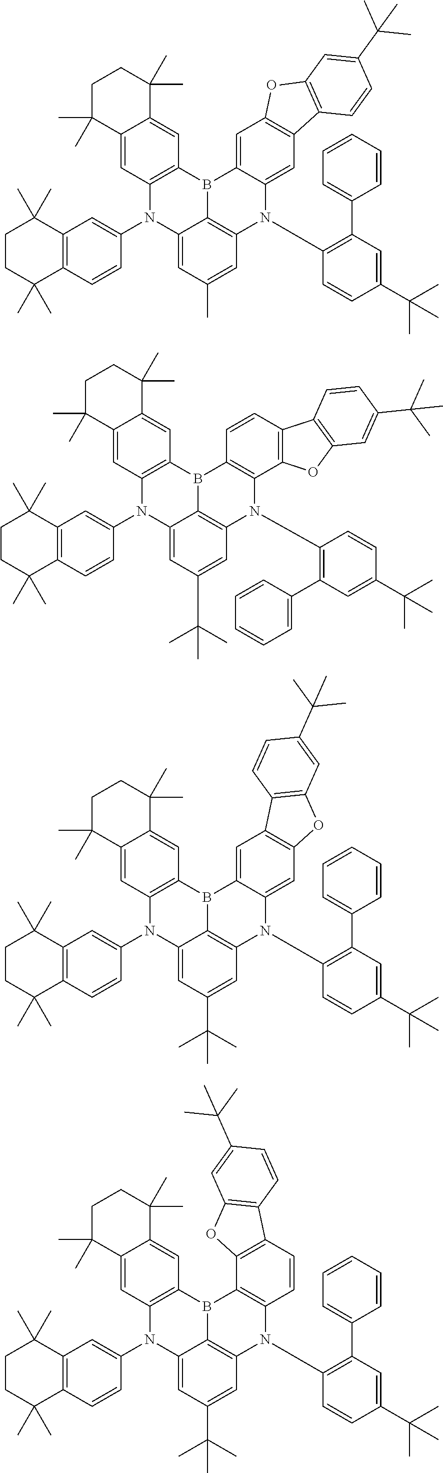

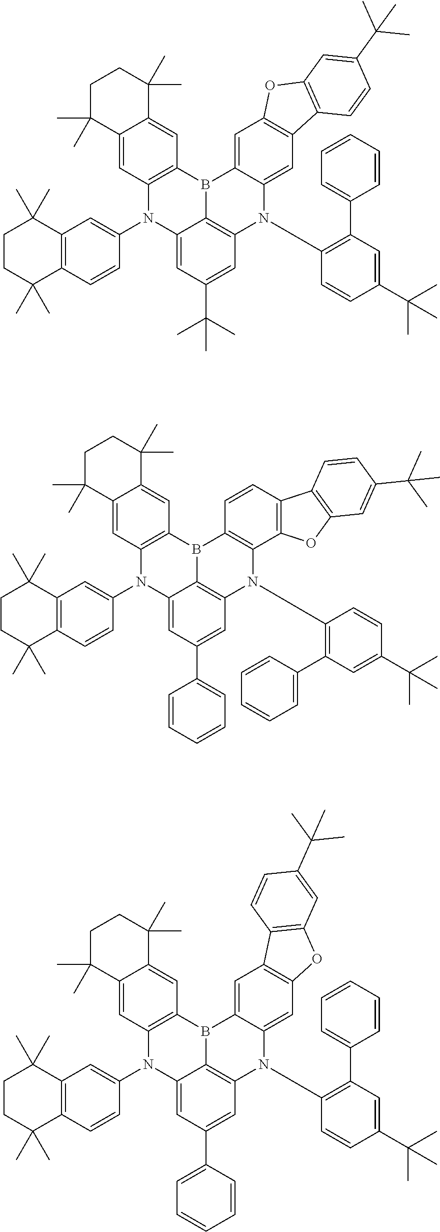 [SMILES: CC(C)(C)c1ccc(N2c3cc4c(cc3B3c5cc6c(cc5N(c5ccc7c(c5)C(C)(C)CCC7(C)C)c5cc(C(C)(C)C)cc2c53)C(C)(C)CCC6(C)C)oc2cc(C(C)(C)C)ccc24)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(oc5cc(C(C)(C)C)ccc54)c32)c(-c2ccccc2)c1 ; CC(C)(C)c1ccc(N2c3cc4oc5cc(C(C)(C)C)ccc5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1]

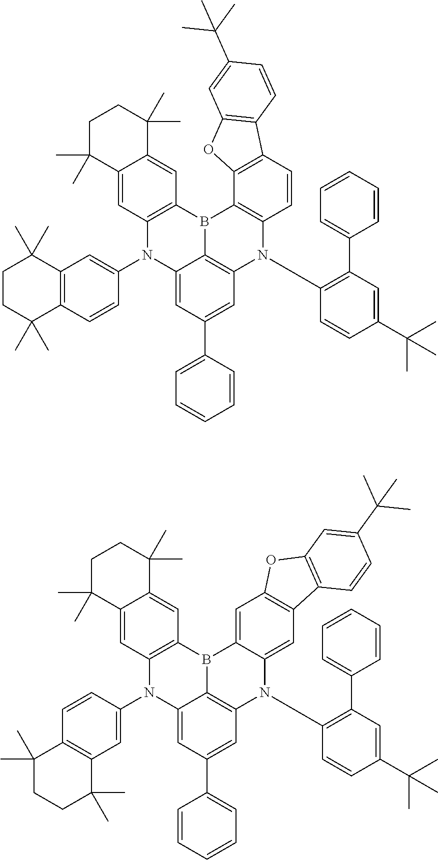

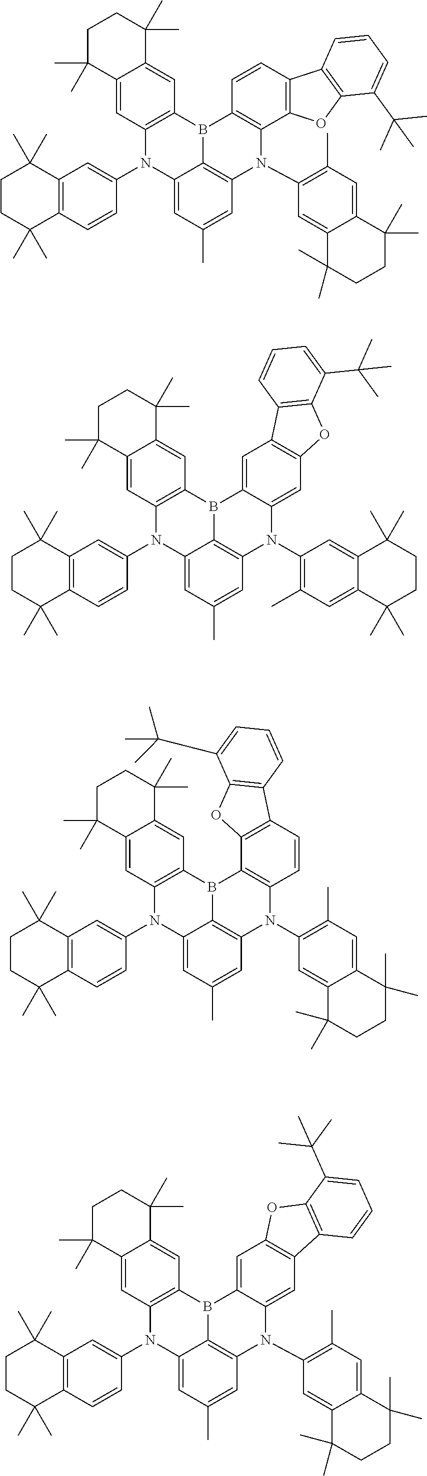

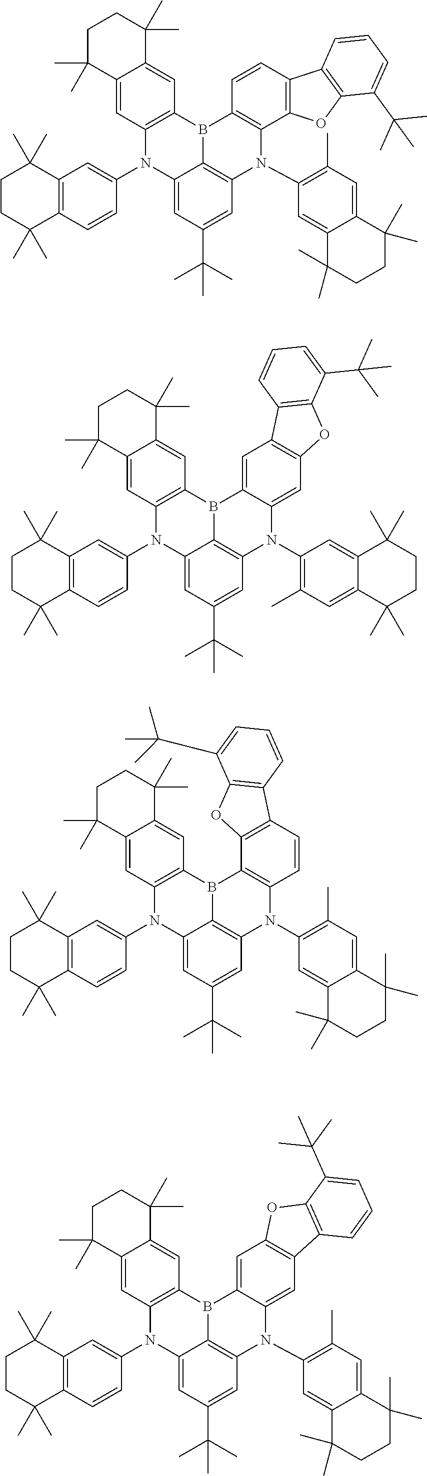

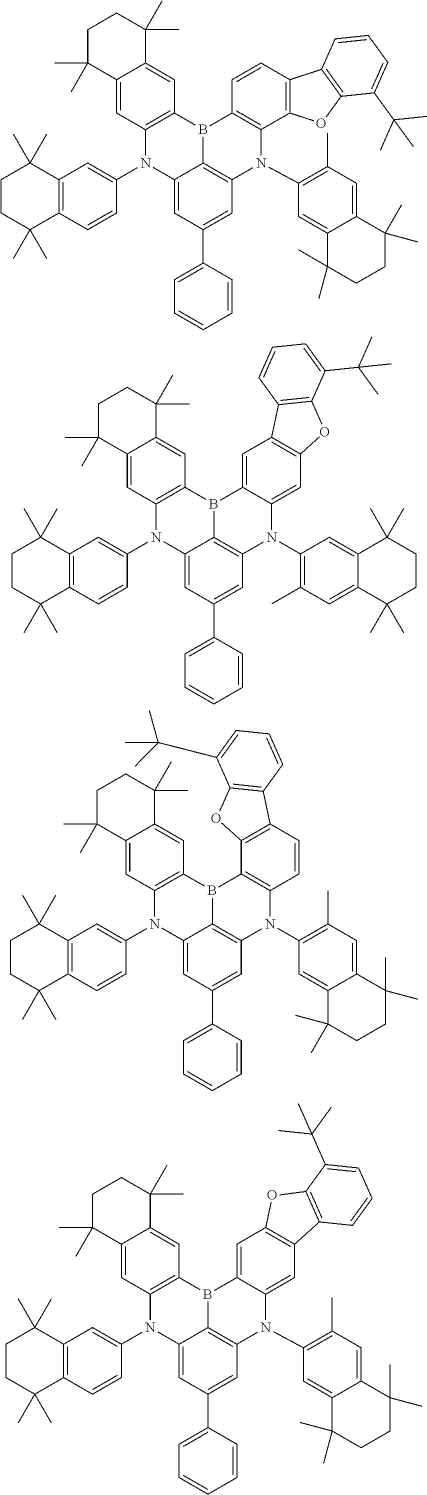

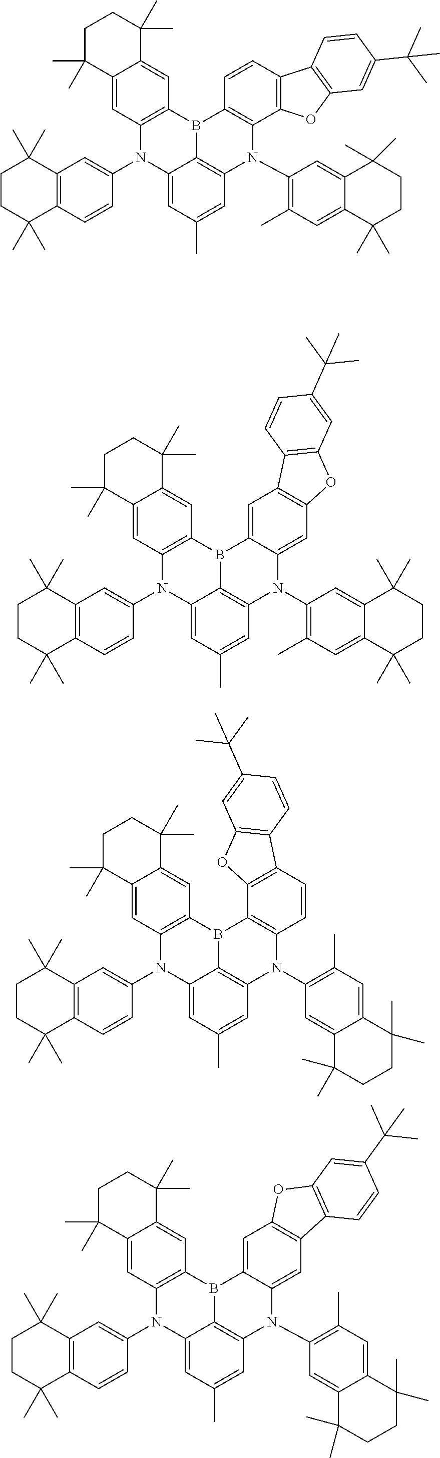

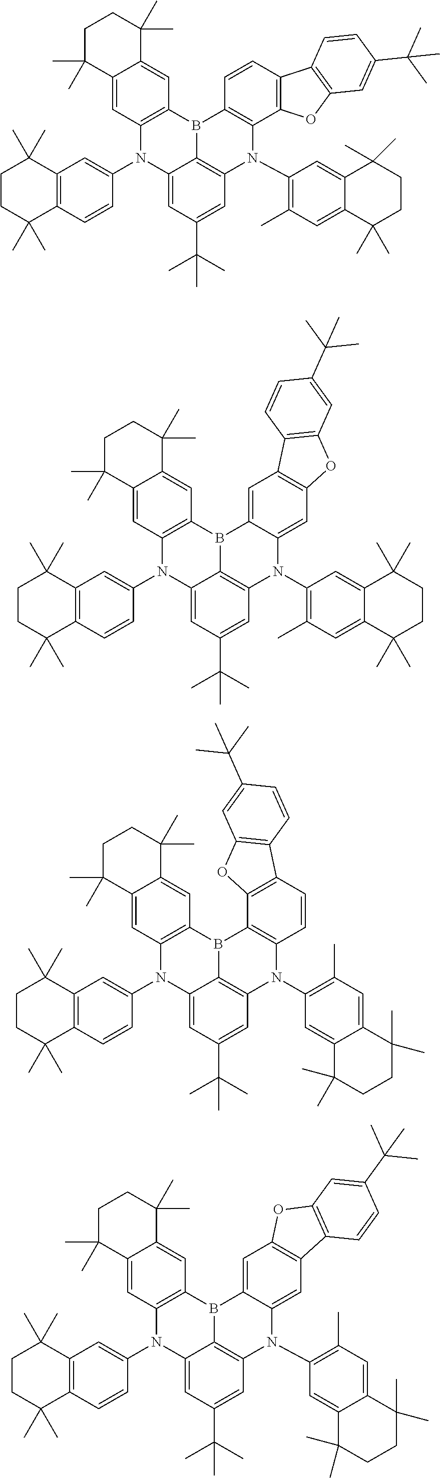

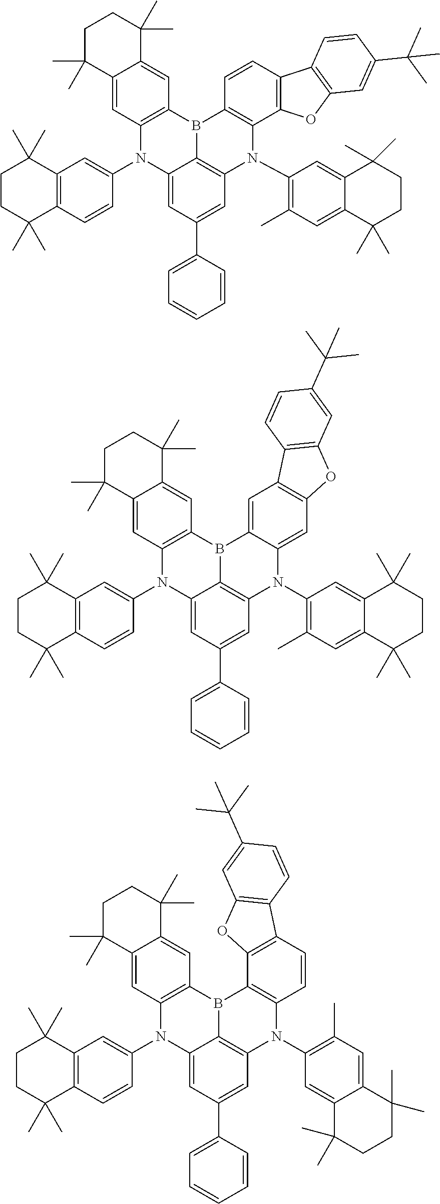

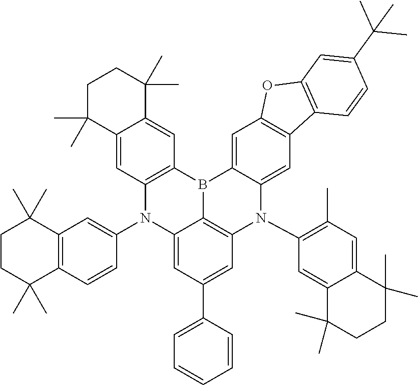 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)oc1cc(C(C)(C)C)ccc14)C(C)(C)CCC2(C)C]

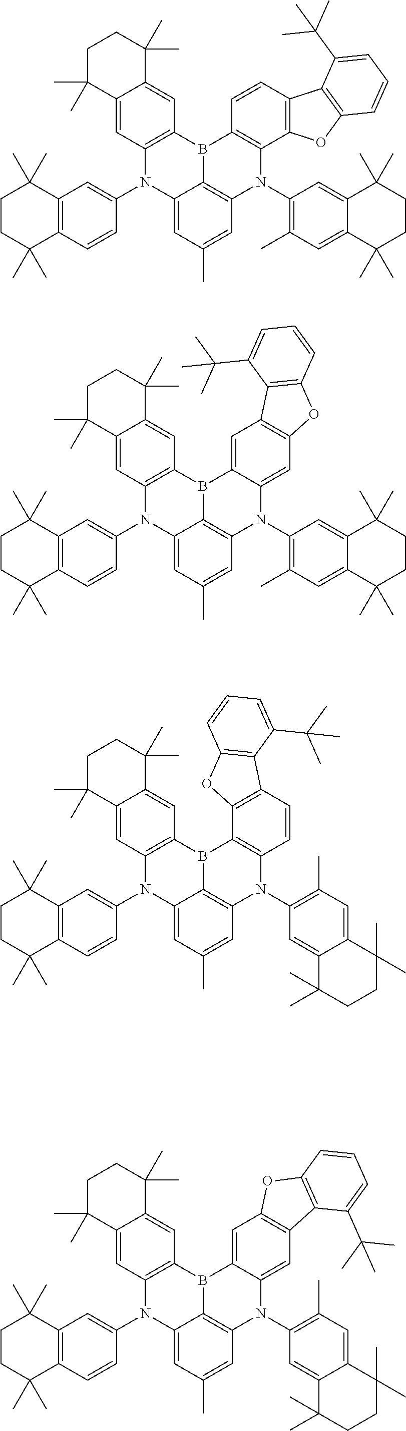

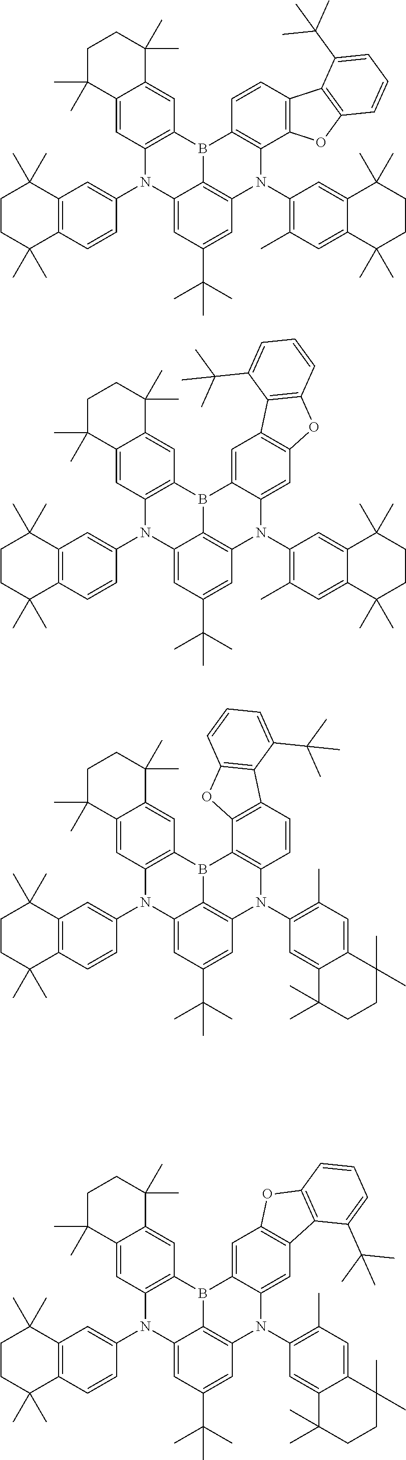

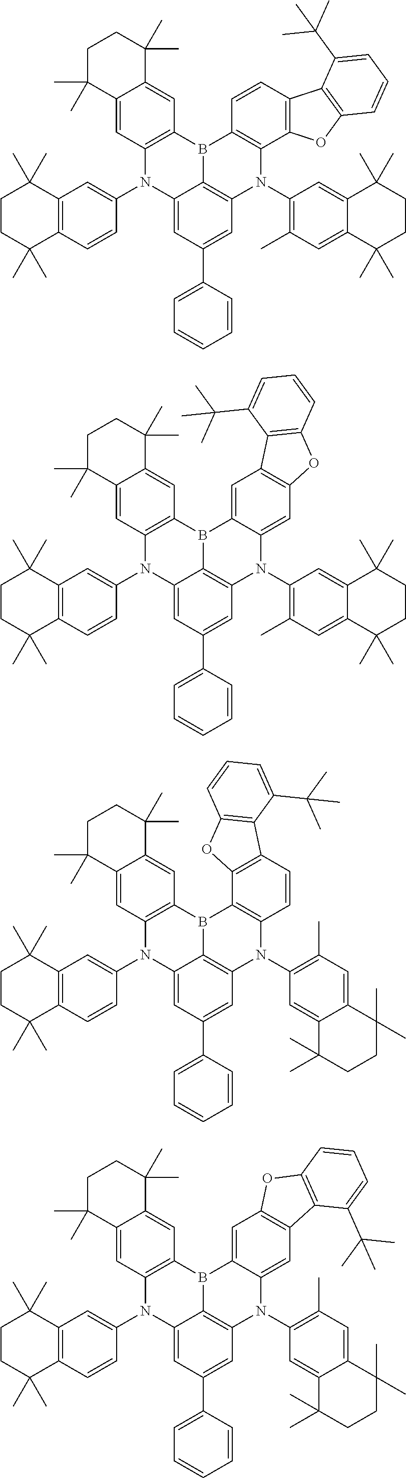

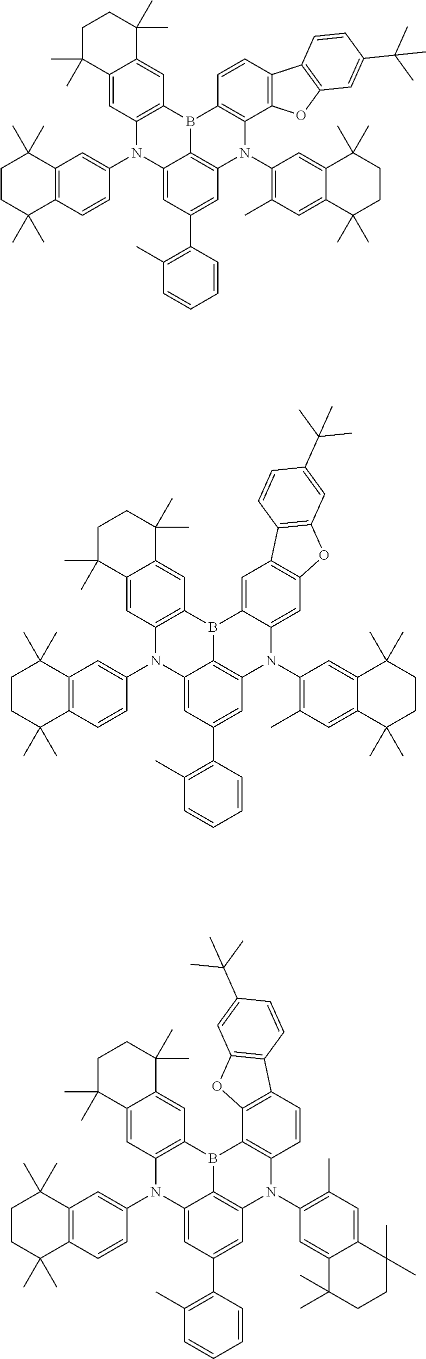 [SMILES: Cc1ccccc1-c1cc2c3c(c1)N(c1cc4c(cc1C)C(C)(C)CCC4(C)C)c1c(ccc4c1oc1cc(C(C)(C)C)ccc14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4oc5cc(C(C)(C)C)ccc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1ccc4c(oc5cc(C(C)(C)C)ccc54)c1B3c1cc3c(cc1N2c1ccc2c(c1)C(C)(C)CCC2(C)C)C(C)(C)CCC3(C)C]

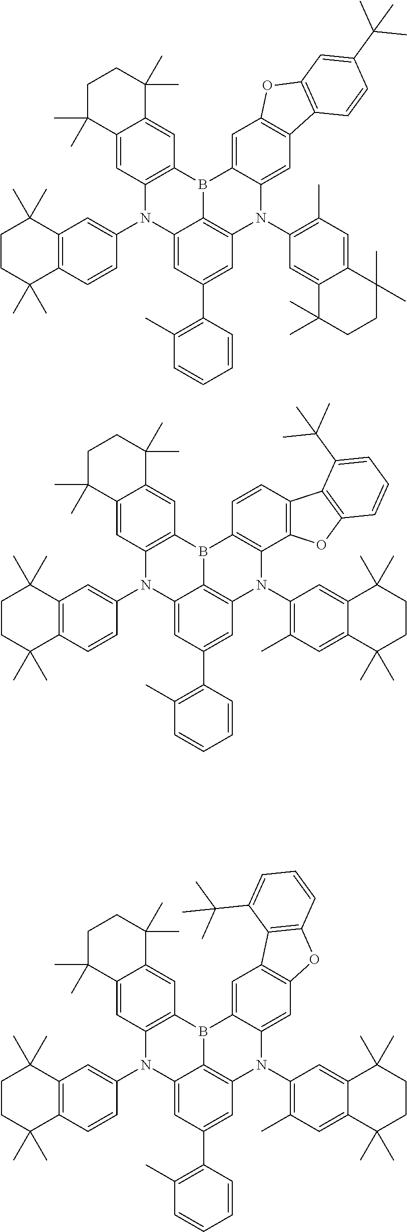 [SMILES: Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)oc1cc(C(C)(C)C)ccc14 ; Cc1ccccc1-c1cc2c3c(c1)N(c1cc4c(cc1C)C(C)(C)CCC4(C)C)c1c(ccc4c1oc1cccc(C(C)(C)C)c14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4oc5cccc(C(C)(C)C)c5c4cc1B3c1cc3c(cc1N2c1ccc2c(c1)C(C)(C)CCC2(C)C)C(C)(C)CCC3(C)C]

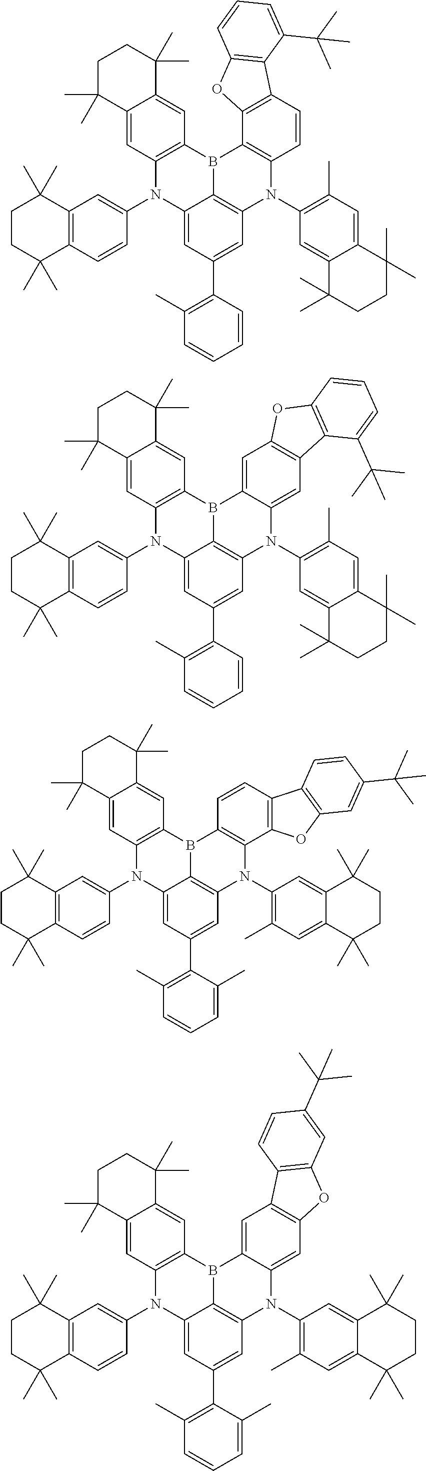

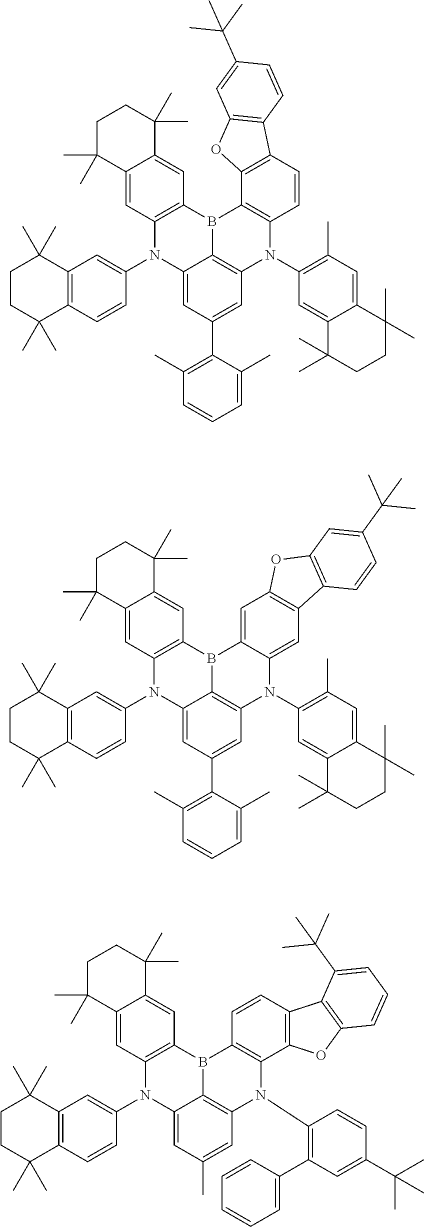 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3oc3cc(C(C)(C)C)ccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)oc1cc(C(C)(C)C)ccc14)C(C)(C)CCC2(C)C ; Cc1cc2c3c(c1)N(c1ccc(C(C)(C)C)cc1-c1ccccc1)c1c(ccc4c1oc1cccc(C(C)(C)C)c14)B3c1cc3c(cc1N2c1ccc2c(c1)C(C)(C)CCC2(C)C)C(C)(C)CCC3(C)C]

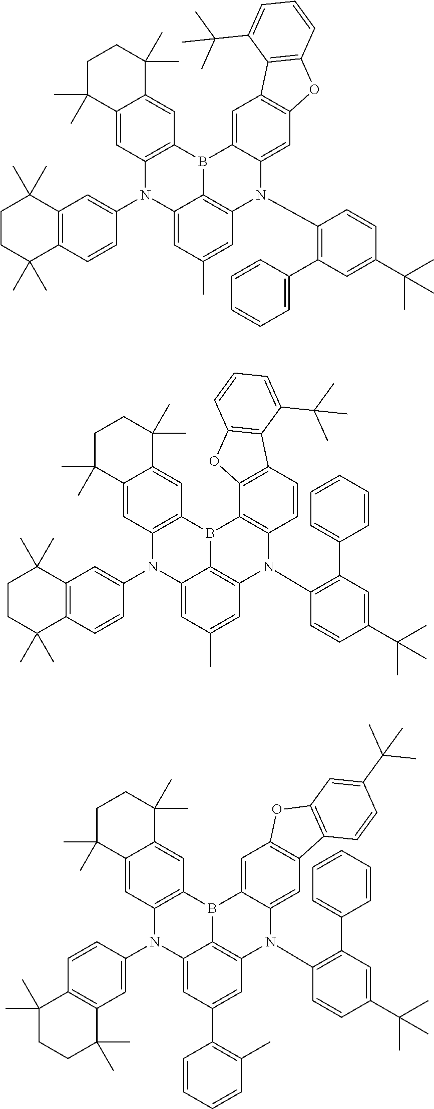

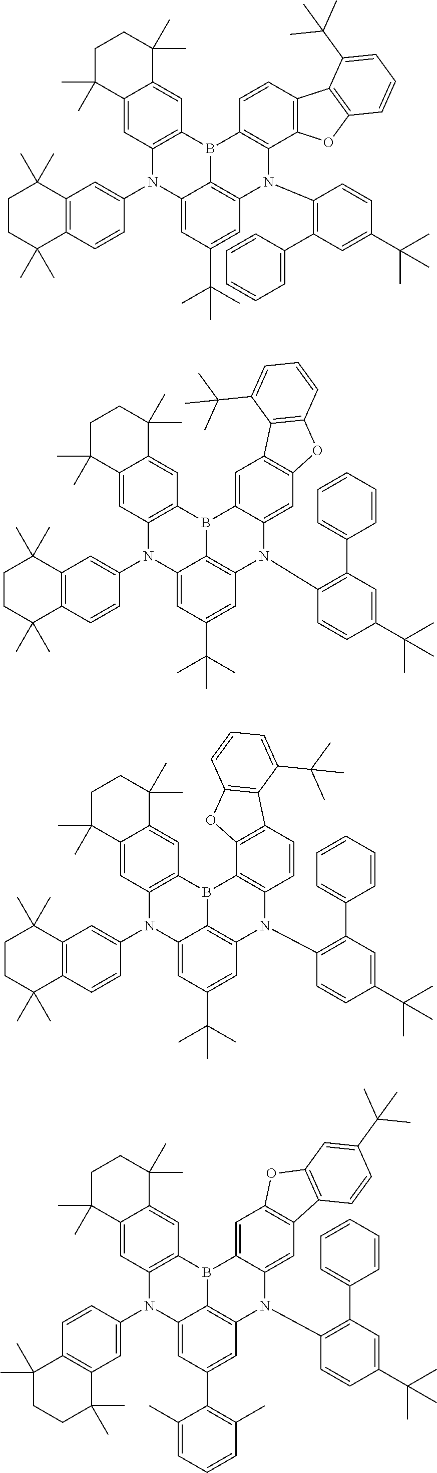

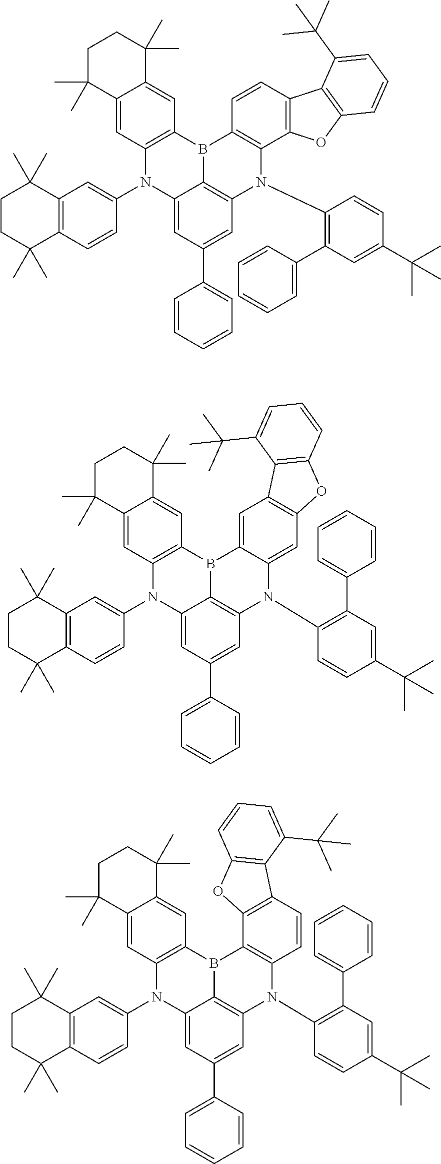 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(oc5cccc(C(C)(C)C)c54)c32)c(-c2ccccc2)c1 ; CC(C)(C)c1ccc(N2c3cc4oc5cccc(C(C)(C)C)c5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3oc3cccc(C(C)(C)C)c32)c(-c2ccccc2)c1]

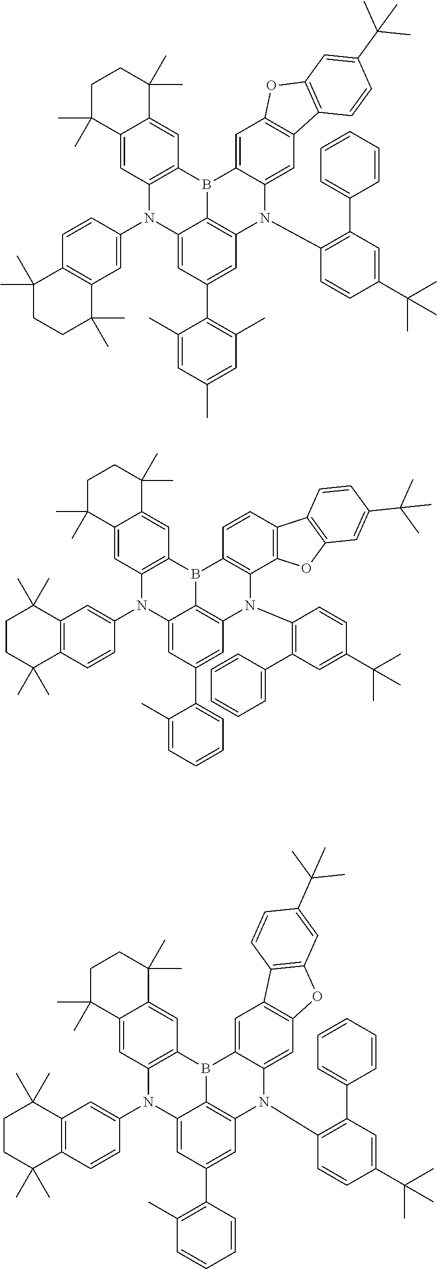 [SMILES: Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2cc(C(C)(C)C)ccc25)c(C)c1 ; Cc1ccccc1-c1cc2c3c(c1)N(c1ccc(C(C)(C)C)cc1-c1ccccc1)c1c(ccc4c1oc1cc(C(C)(C)C)ccc14)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4oc5cc(C(C)(C)C)ccc5c4cc1B3c1cc3c(cc1N2c1ccc2c(c1)C(C)(C)CCC2(C)C)C(C)(C)CCC3(C)C]

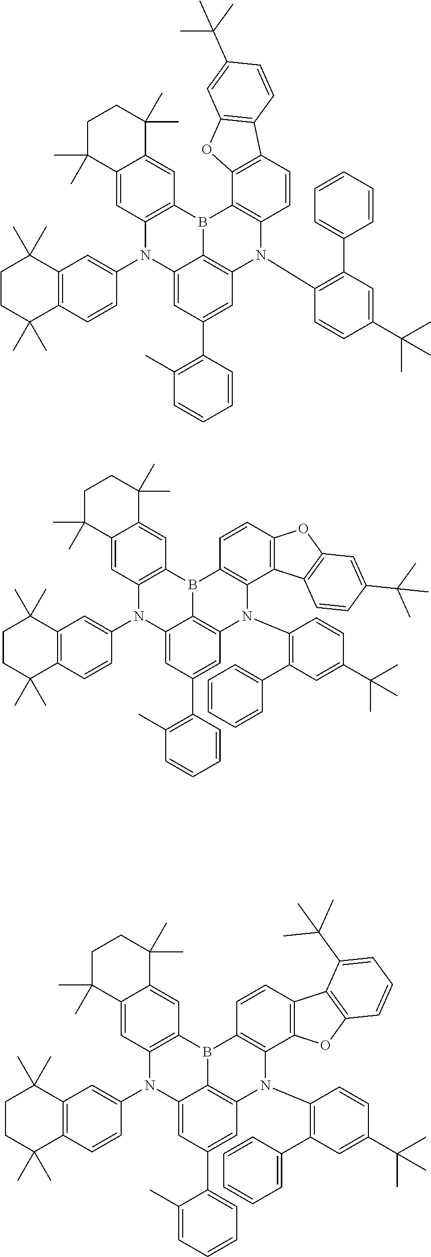 [SMILES: Cc1ccccc1-c1cc2c3c(c1)N(c1ccc(C(C)(C)C)cc1-c1ccccc1)c1ccc4c(oc5cc(C(C)(C)C)ccc54)c1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4oc5cc(C(C)(C)C)ccc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4c1oc1cccc(C(C)(C)C)c14)B3c1cc3c(cc1N2c1ccc2c(c1)C(C)(C)CCC2(C)C)C(C)(C)CCC3(C)C]

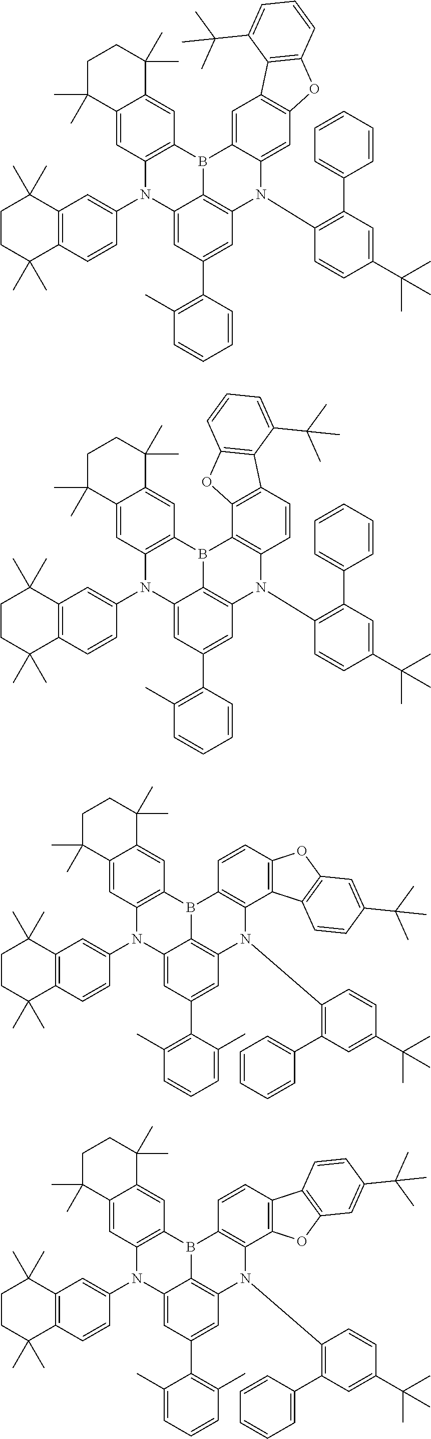

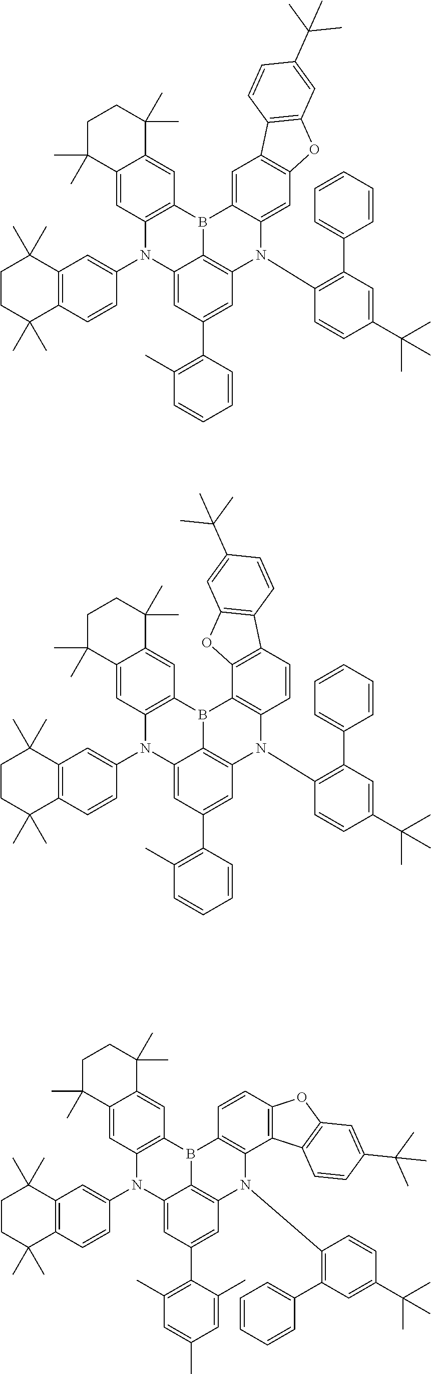 [SMILES: Cc1ccccc1-c1cc2c3c(c1)N(c1ccc(C(C)(C)C)cc1-c1ccccc1)c1cc4oc5cc(C(C)(C)C)ccc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1ccc4c(oc5cc(C(C)(C)C)ccc54)c1B3c1cc3c(cc1N2c1ccc2c(c1)C(C)(C)CCC2(C)C)C(C)(C)CCC3(C)C ; Cc1cc(C)c(-c2cc3c4c(c2)N(c2ccc(C(C)(C)C)cc2-c2ccccc2)c2c(ccc5oc6cc(C(C)(C)C)ccc6c25)B4c2cc4c(cc2N3c2ccc3c(c2)C(C)(C)CCC3(C)C)C(C)(C)CCC4(C)C)c(C)c1]

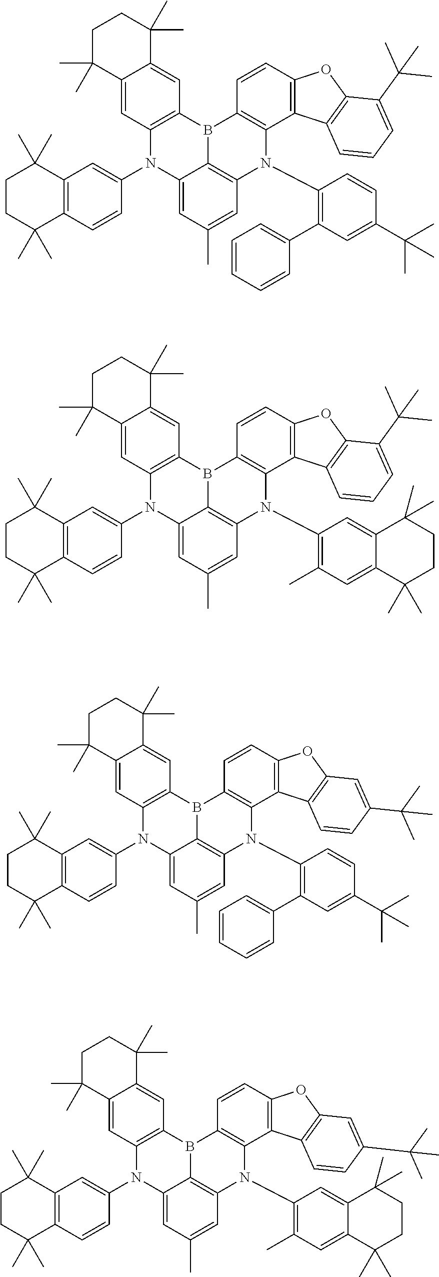

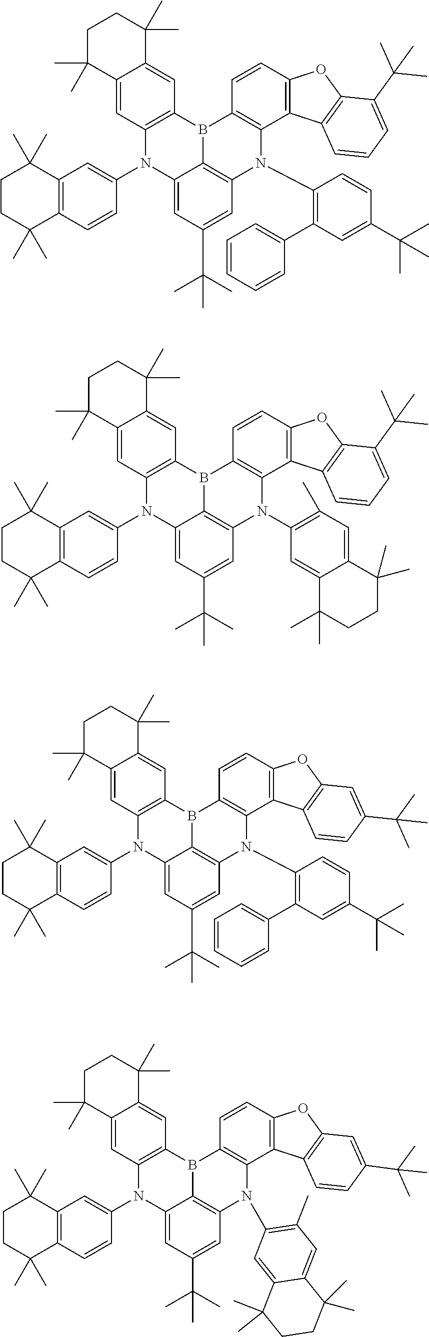

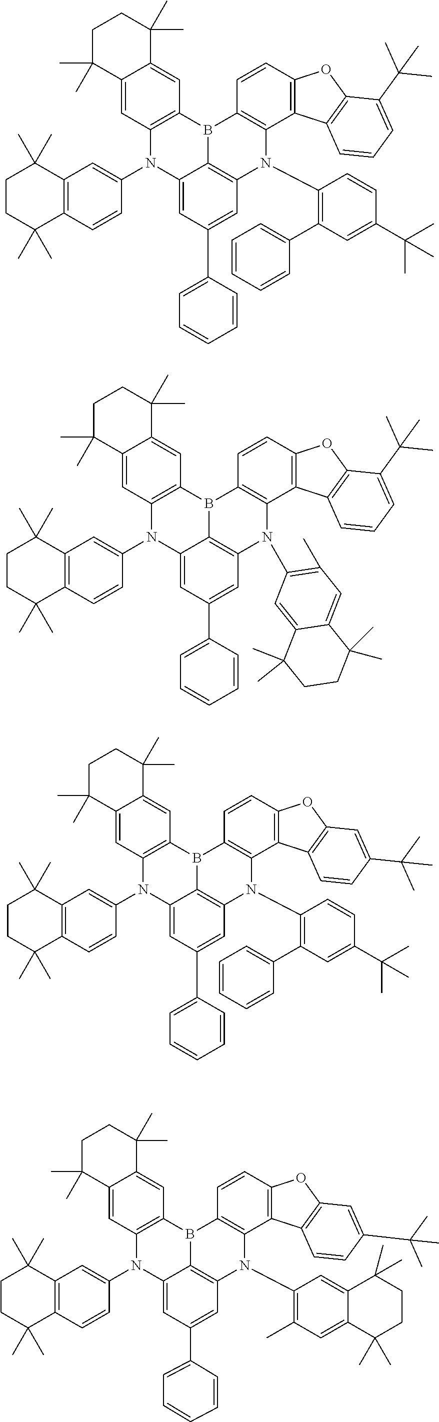

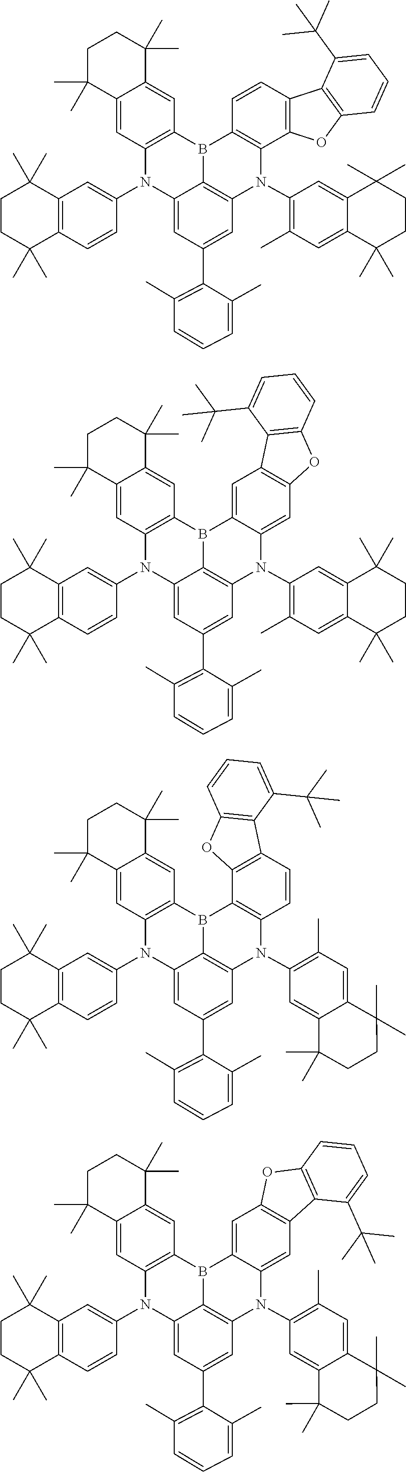

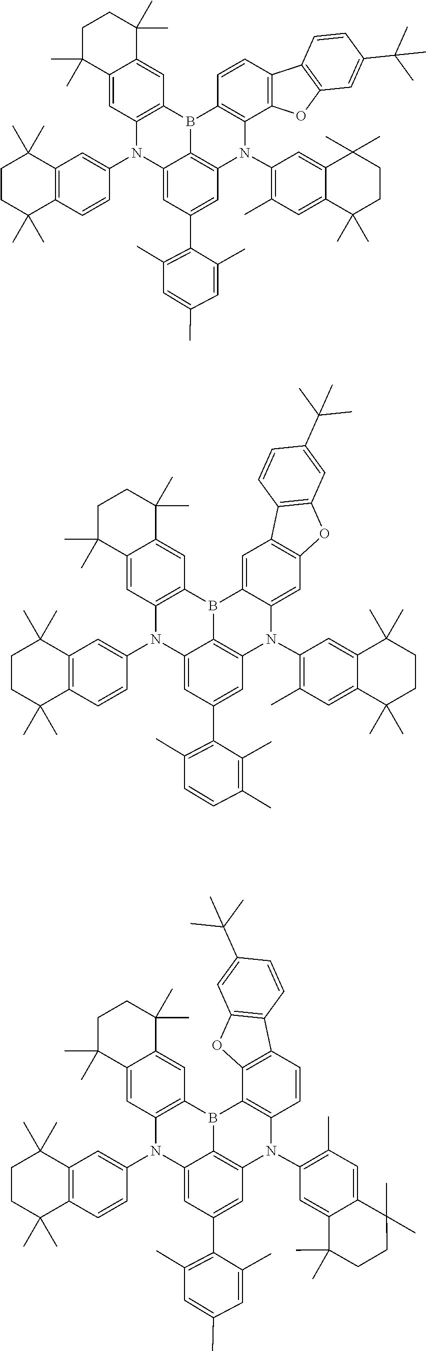 [SMILES: Cc1cc(C)c(-c2cc3c4c(c2)N(c2cc5c(cc2C)C(C)(C)CCC5(C)C)c2c(ccc5c2oc2cc(C(C)(C)C)ccc25)B4c2cc4c(cc2N3c2ccc3c(c2)C(C)(C)CCC3(C)C)C(C)(C)CCC4(C)C)c(C)c1 ; Cc1cc2c(cc1N1c3cc4oc5cc(C(C)(C)C)ccc5c4cc3B3c4cc5c(cc4N(c4ccc6c(c4)C(C)(C)CCC6(C)C)c4cc(-c6c(C)ccc(C)c6C)cc1c43)C(C)(C)CCC5(C)C)C(C)(C)CCC2(C)C ; Cc1cc(C)c(-c2cc3c4c(c2)N(c2cc5c(cc2C)C(C)(C)CCC5(C)C)c2ccc5c(oc6cc(C(C)(C)C)ccc65)c2B4c2cc4c(cc2N3c2ccc3c(c2)C(C)(C)CCC3(C)C)C(C)(C)CCC4(C)C)c(C)c1]

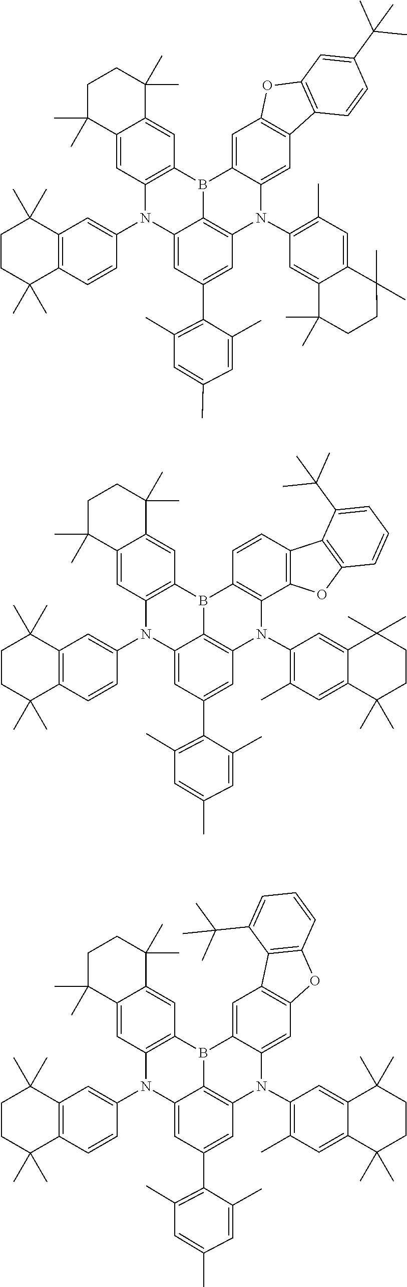 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2cc(C(C)(C)C)ccc25)c(C)c1 ; Cc1cc(C)c(-c2cc3c4c(c2)N(c2cc5c(cc2C)C(C)(C)CCC5(C)C)c2c(ccc5c2oc2cccc(C(C)(C)C)c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5oc6cccc(C(C)(C)C)c6c5cc2B4c2cc4c(cc2N3c2ccc3c(c2)C(C)(C)CCC3(C)C)C(C)(C)CCC4(C)C)c(C)c1]

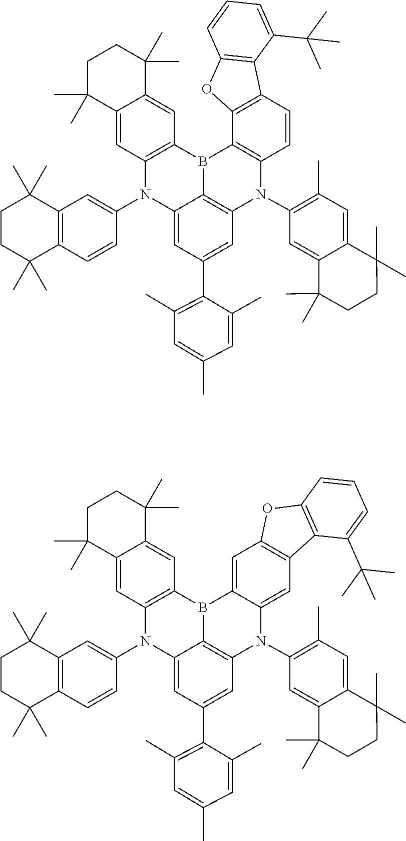 [SMILES: Cc1cc(C)c(-c2cc3c4c(c2)N(c2cc5c(cc2C)C(C)(C)CCC5(C)C)c2ccc5c(oc6cccc(C(C)(C)C)c65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)oc2cccc(C(C)(C)C)c25)c(C)c1]

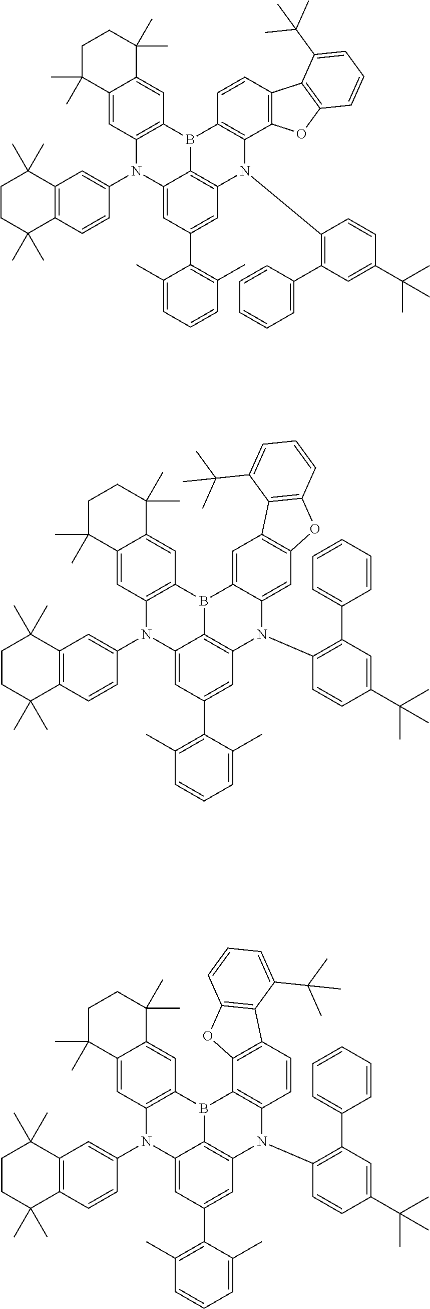 [SMILES: Cc1cccc(C)c1-c1cc2c3c(c1)N(c1ccc(C(C)(C)C)cc1-c1ccccc1)c1c(ccc4c1oc1cccc(C(C)(C)C)c14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4oc5cccc(C(C)(C)C)c5c4cc1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1ccc4c(oc5cccc(C(C)(C)C)c54)c1B3c1cc3c(cc1N2c1ccc2c(c1)C(C)(C)CCC2(C)C)C(C)(C)CCC3(C)C]

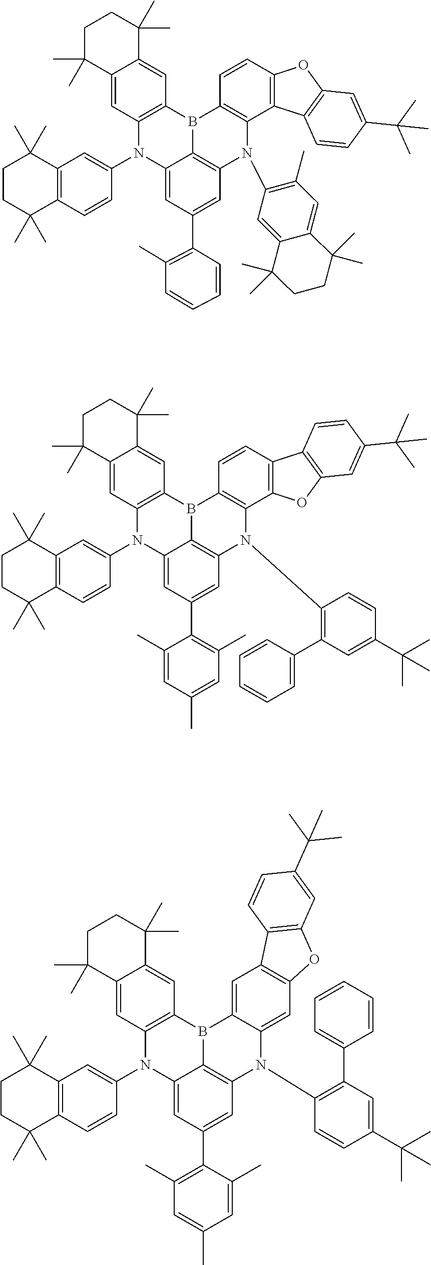 [SMILES: Cc1ccccc1-c1cc2c3c(c1)N(c1cc4c(cc1C)C(C)(C)CCC4(C)C)c1c(ccc4oc5cc(C(C)(C)C)ccc5c14)B3c1cc3c(cc1N2c1ccc2c(c1)C(C)(C)CCC2(C)C)C(C)(C)CCC3(C)C ; Cc1cc(C)c(-c2cc3c4c(c2)N(c2ccc(C(C)(C)C)cc2-c2ccccc2)c2c(ccc5c2oc2cc(C(C)(C)C)ccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5oc6cc(C(C)(C)C)ccc6c5cc2B4c2cc4c(cc2N3c2ccc3c(c2)C(C)(C)CCC3(C)C)C(C)(C)CCC4(C)C)c(C)c1]

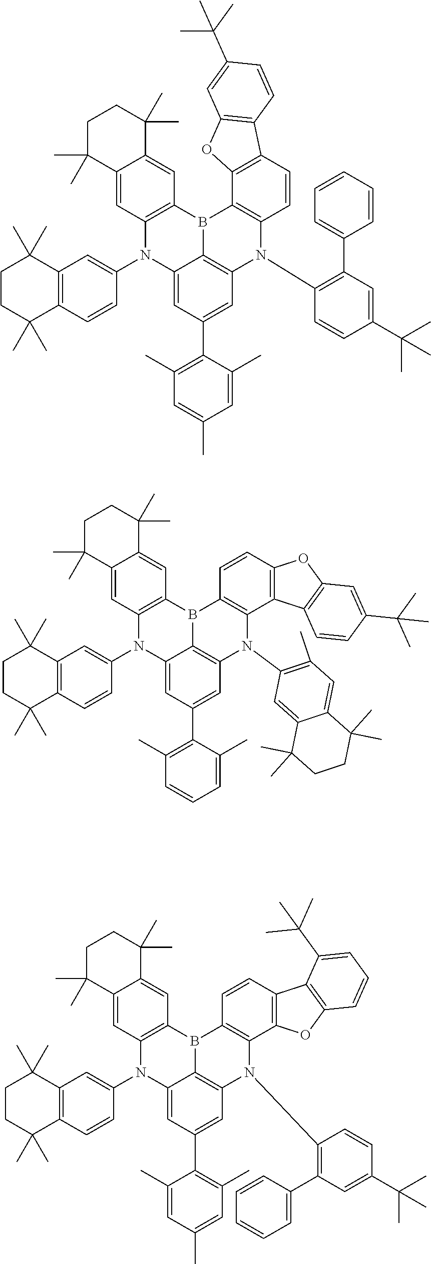 [SMILES: Cc1cc(C)c(-c2cc3c4c(c2)N(c2ccc(C(C)(C)C)cc2-c2ccccc2)c2ccc5c(oc6cc(C(C)(C)C)ccc65)c2B4c2cc4c(cc2N3c2ccc3c(c2)C(C)(C)CCC3(C)C)C(C)(C)CCC4(C)C)c(C)c1 ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4oc5cc(C(C)(C)C)ccc5c4c31)C(C)(C)CCC2(C)C ; Cc1cc(C)c(-c2cc3c4c(c2)N(c2ccc(C(C)(C)C)cc2-c2ccccc2)c2c(ccc5c2oc2cccc(C(C)(C)C)c25)B4c2cc4c(cc2N3c2ccc3c(c2)C(C)(C)CCC3(C)C)C(C)(C)CCC4(C)C)c(C)c1]

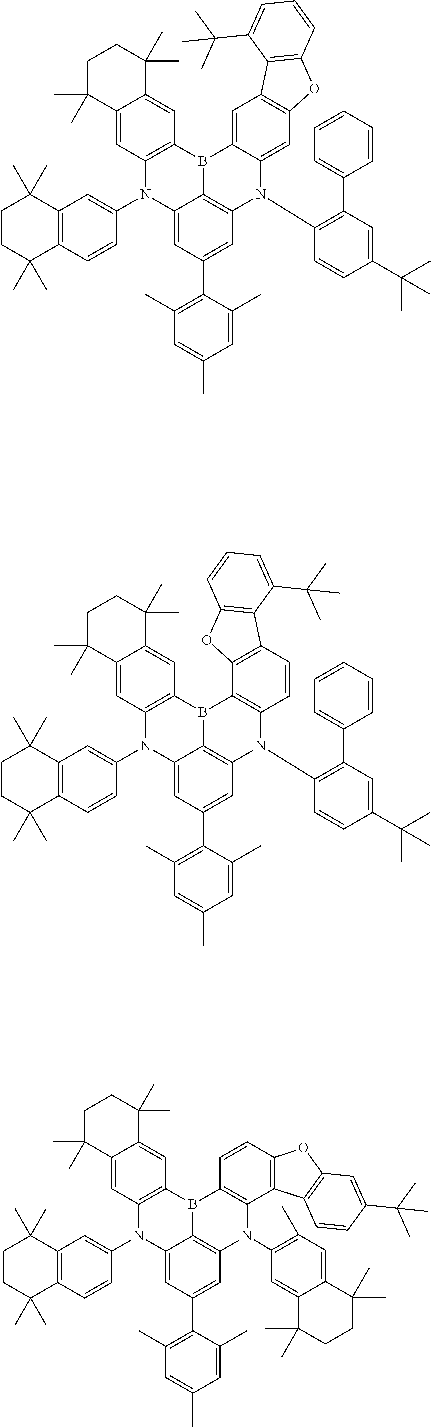 [SMILES: Cc1cc(C)c(-c2cc3c4c(c2)N(c2ccc(C(C)(C)C)cc2-c2ccccc2)c2cc5oc6cccc(C(C)(C)C)c6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2ccc5c(oc6cccc(C(C)(C)C)c65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5oc6cc(C(C)(C)C)ccc6c25)B4c2cc4c(cc2N3c2ccc3c(c2)C(C)(C)CCC3(C)C)C(C)(C)CCC4(C)C)c(C)c1]

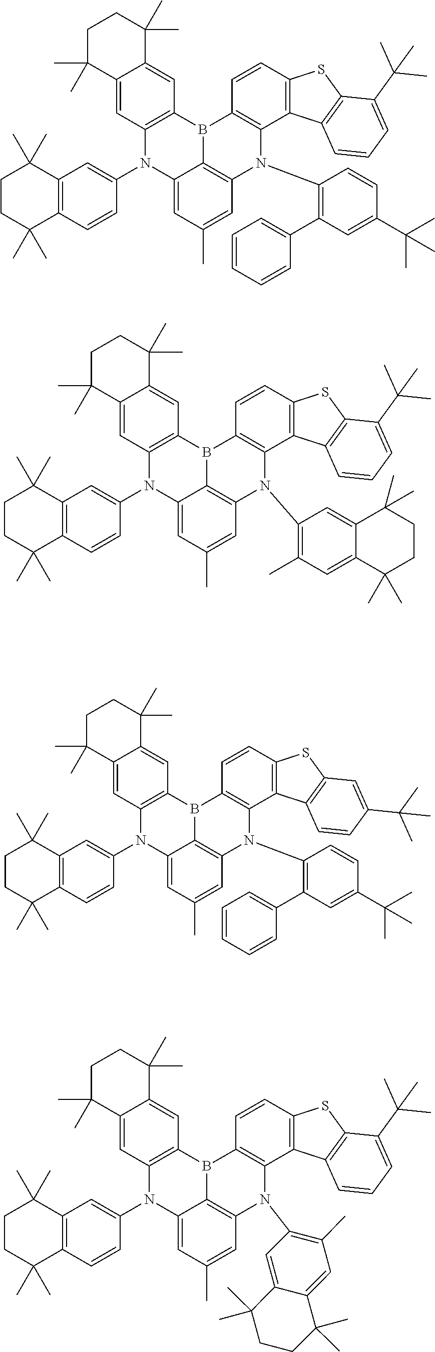

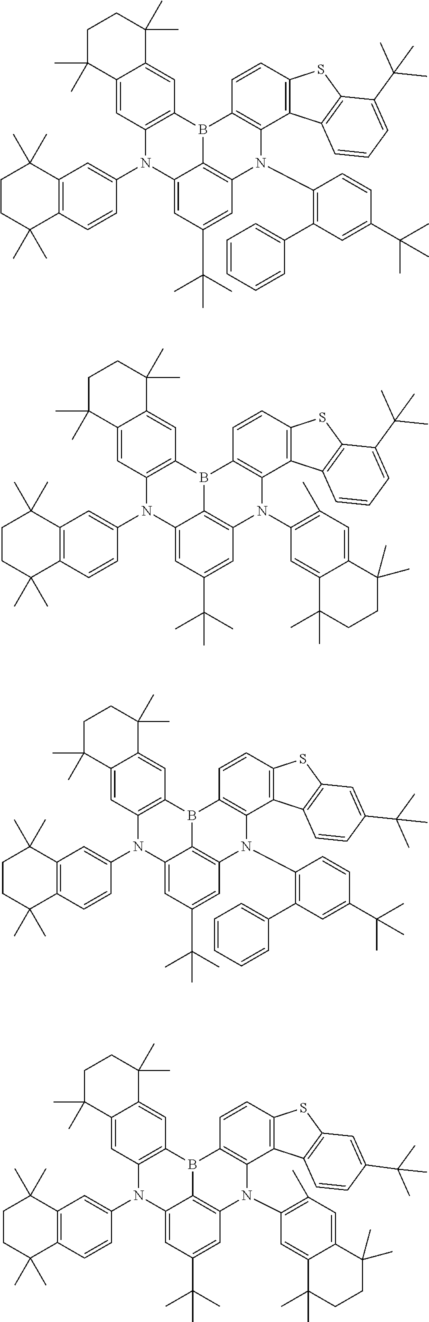

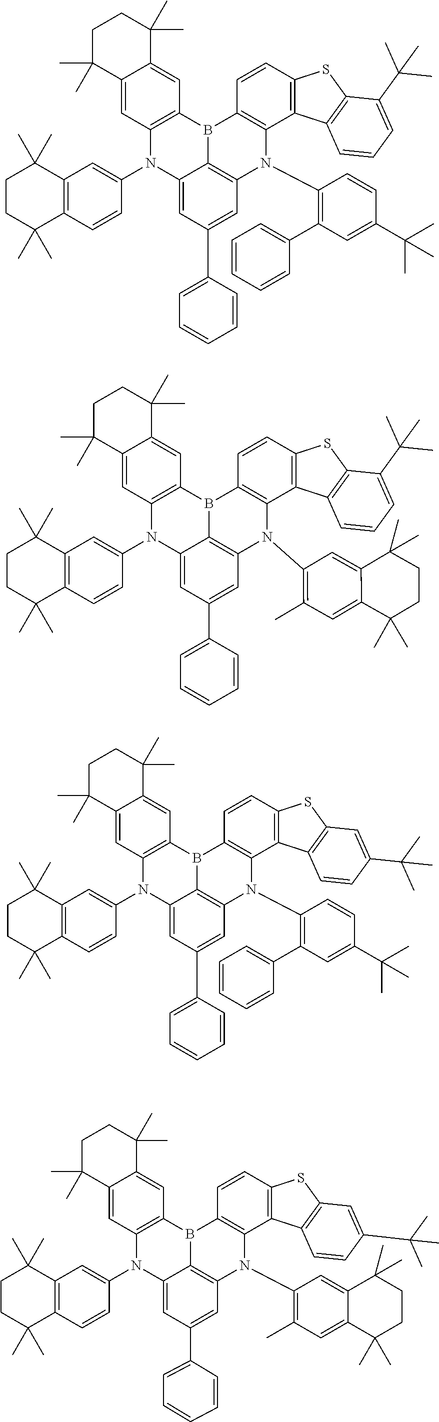

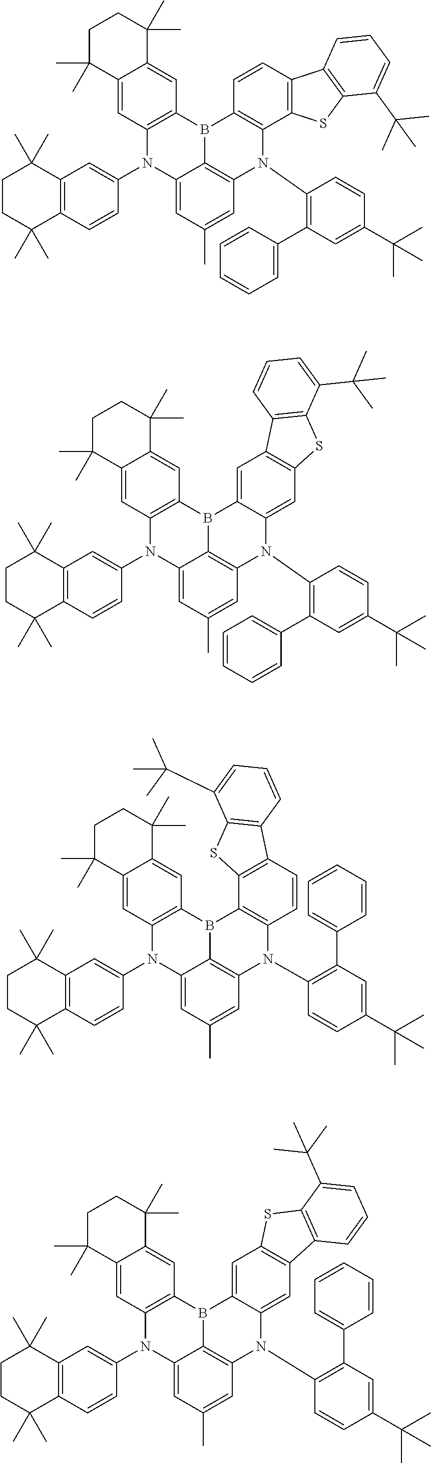

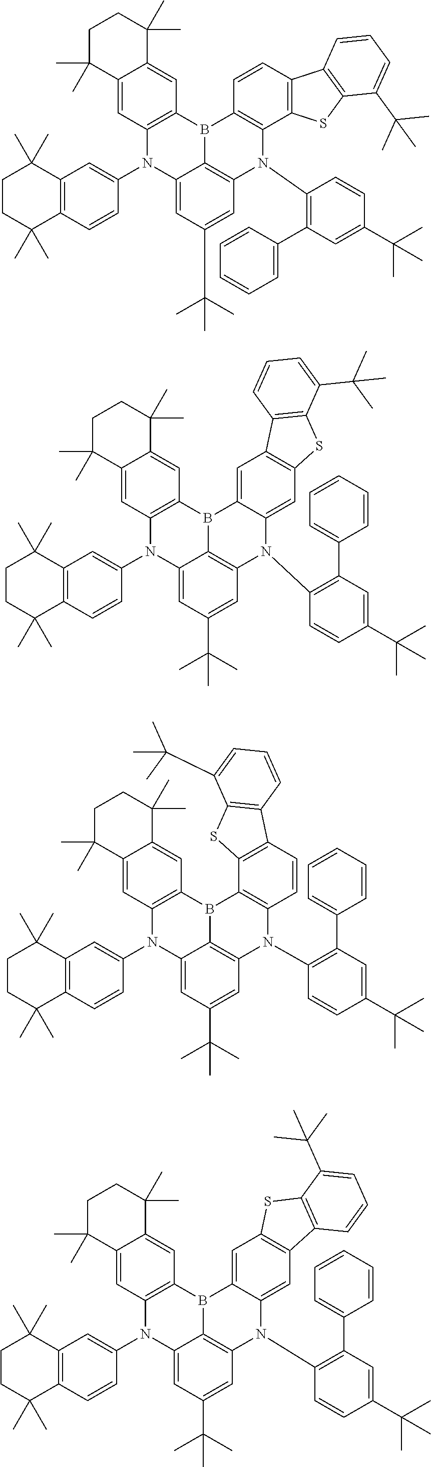

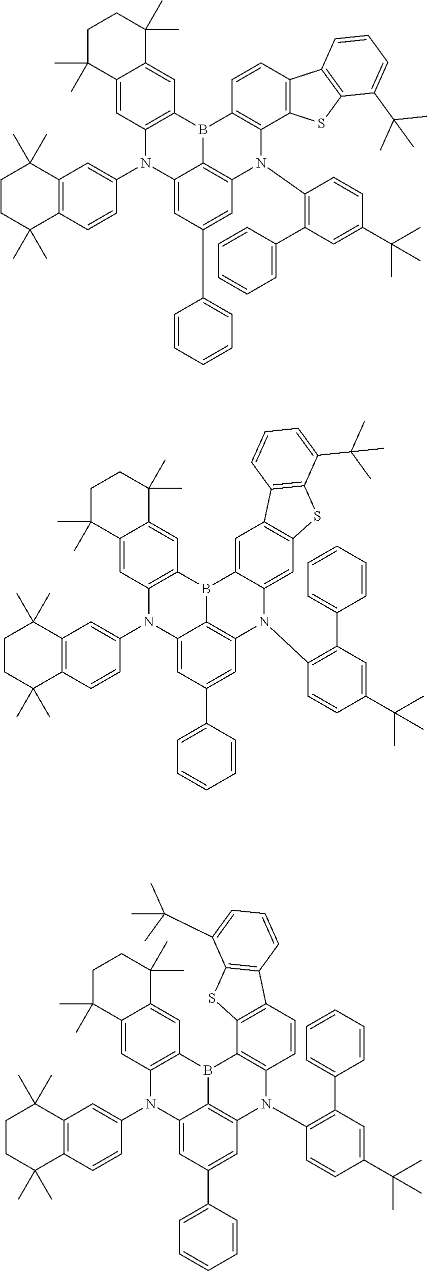 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(sc5c(C(C)(C)C)cccc54)c32)c(-c2ccccc2)c1 ; CC(C)(C)c1ccc(N2c3cc4sc5c(C(C)(C)C)cccc5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3sc3c(C(C)(C)C)cccc32)c(-c2ccccc2)c1]

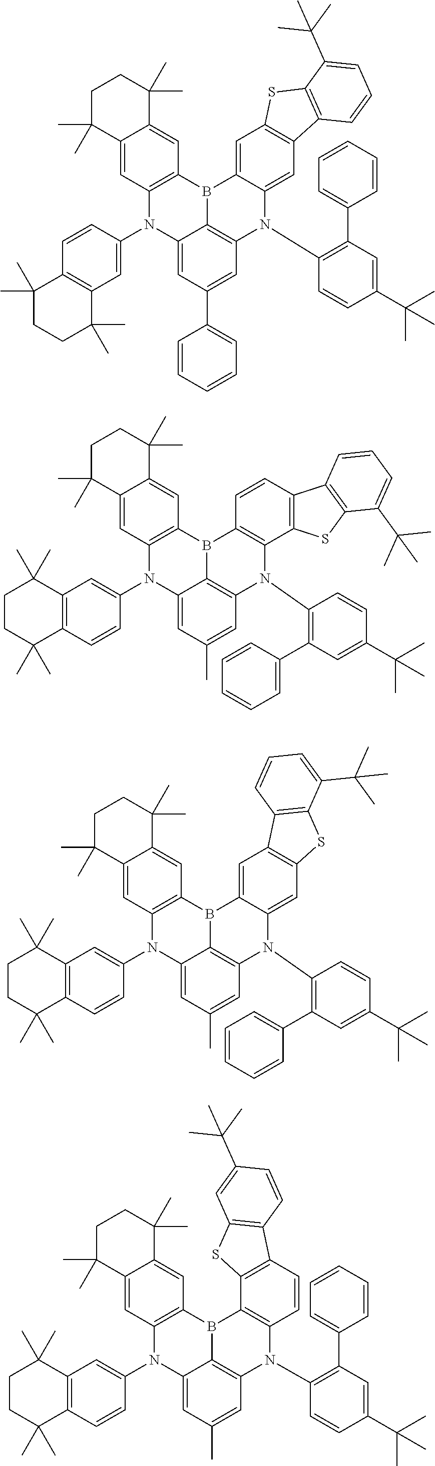

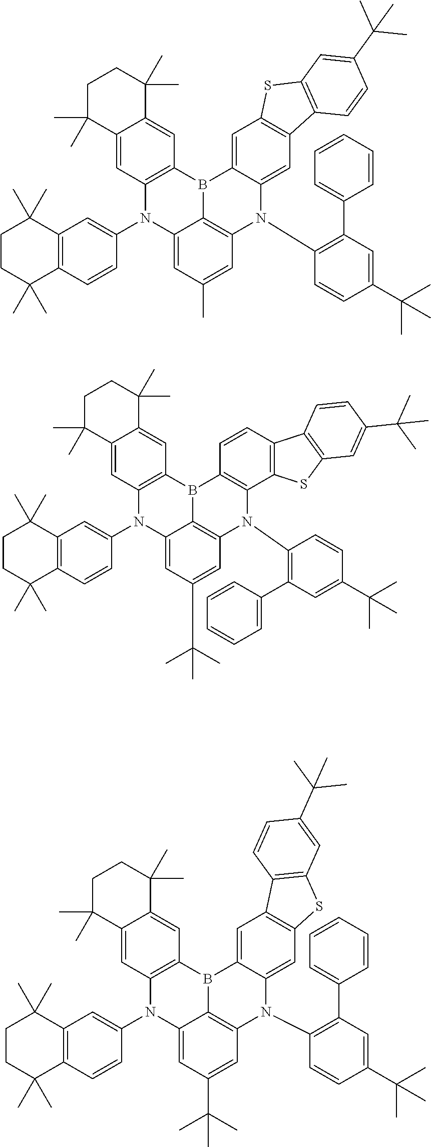 [SMILES: Cc1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1cc(C(C)(C)C)ccc14 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3ccc4c(sc5cc(C(C)(C)C)ccc54)c32)c(-c2ccccc2)c1 ; CC(C)(C)c1ccc(N2c3cc4sc5cc(C(C)(C)C)ccc5c4cc3B3c4cc5c(cc4N(c4ccc6c(c4)C(C)(C)CCC6(C)C)c4cc(C(C)(C)C)cc2c43)C(C)(C)CCC5(C)C)c(-c2ccccc2)c1]

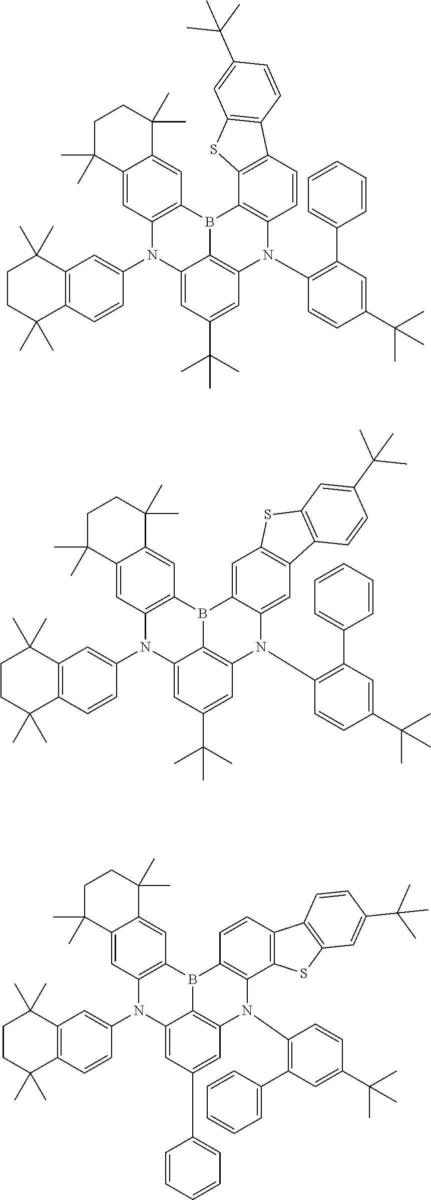 [SMILES: CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3c2ccc2c3sc3cc(C(C)(C)C)ccc32)c(-c2ccccc2)c1 ; CC(C)(C)c1ccc(N2c3cc4c(cc3B3c5cc6c(cc5N(c5ccc7c(c5)C(C)(C)CCC7(C)C)c5cc(C(C)(C)C)cc2c53)C(C)(C)CCC6(C)C)sc2cc(C(C)(C)C)ccc24)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(sc5cc(C(C)(C)C)ccc54)c32)c(-c2ccccc2)c1]

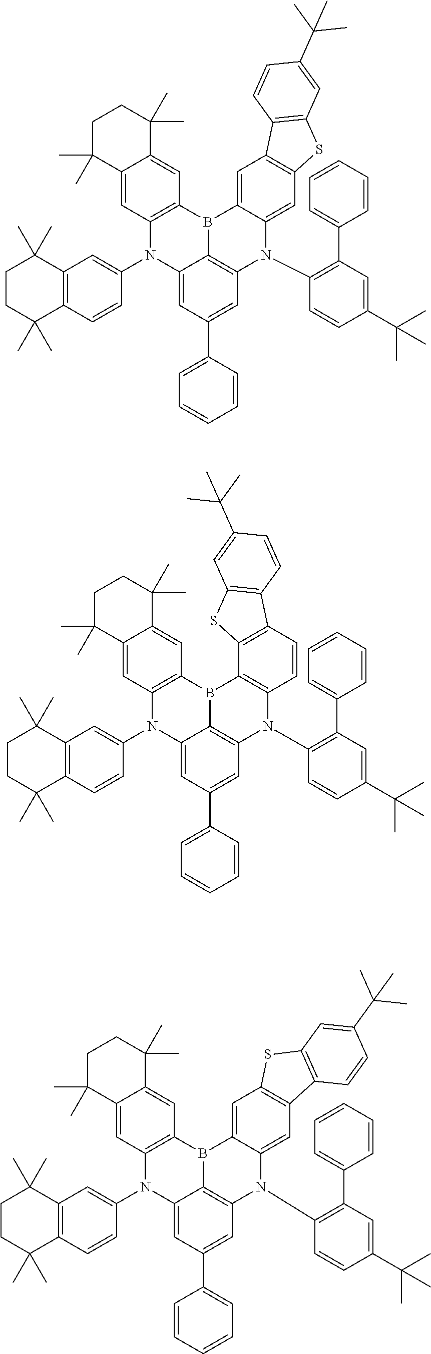 [SMILES: CC(C)(C)c1ccc(N2c3cc4sc5cc(C(C)(C)C)ccc5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3sc3cc(C(C)(C)C)ccc32)c(-c2ccccc2)c1 ; CC(C)(C)c1ccc(N2c3cc4c(cc3B3c5cc6c(cc5N(c5ccc7c(c5)C(C)(C)CCC7(C)C)c5cc(-c7ccccc7)cc2c53)C(C)(C)CCC6(C)C)sc2cc(C(C)(C)C)ccc24)c(-c2ccccc2)c1]

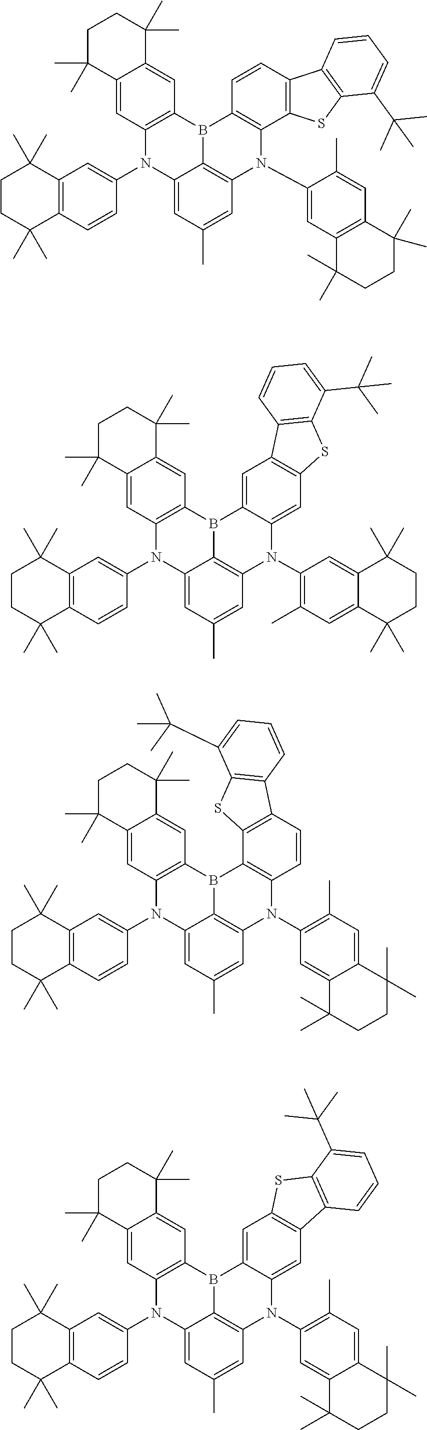

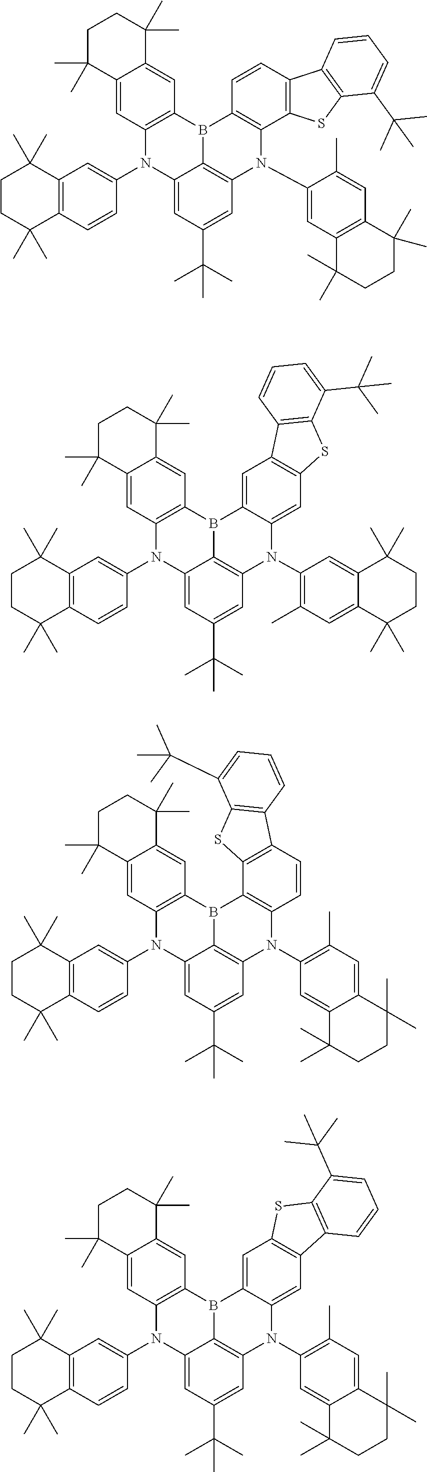

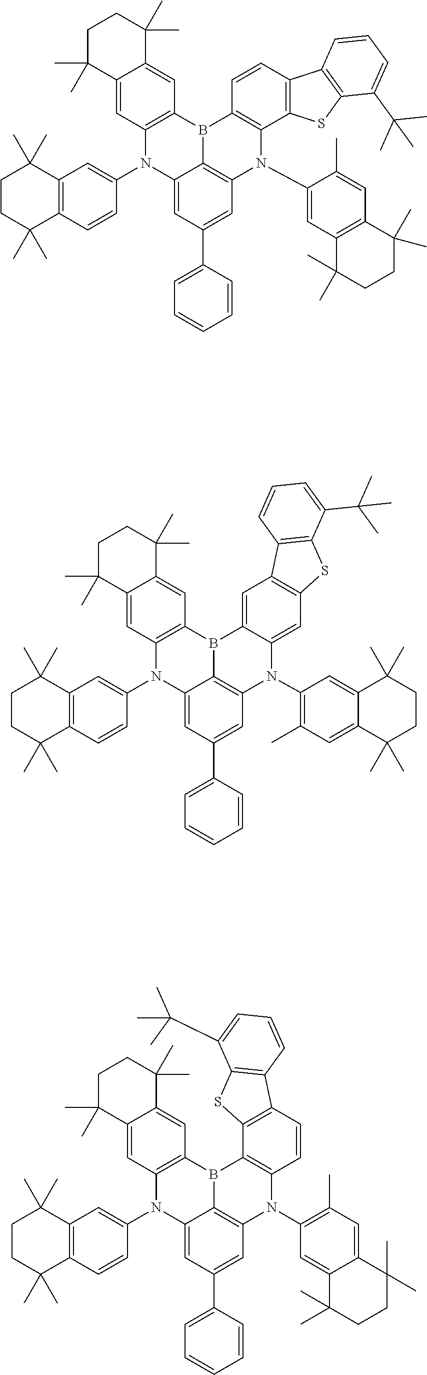 [SMILES: Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3ccc4c(sc5c(C(C)(C)C)cccc54)c31)C(C)(C)CCC2(C)C ; Cc1cc2c(cc1N1c3cc4sc5c(C(C)(C)C)cccc5c4cc3B3c4cc5c(cc4N(c4ccc6c(c4)C(C)(C)CCC6(C)C)c4cc(-c6ccccc6)cc1c43)C(C)(C)CCC5(C)C)C(C)(C)CCC2(C)C ; Cc1cc2c(cc1N1c3cc(-c4ccccc4)cc4c3B(c3cc5c(cc3N4c3ccc4c(c3)C(C)(C)CCC4(C)C)C(C)(C)CCC5(C)C)c3c1ccc1c3sc3c(C(C)(C)C)cccc31)C(C)(C)CCC2(C)C]

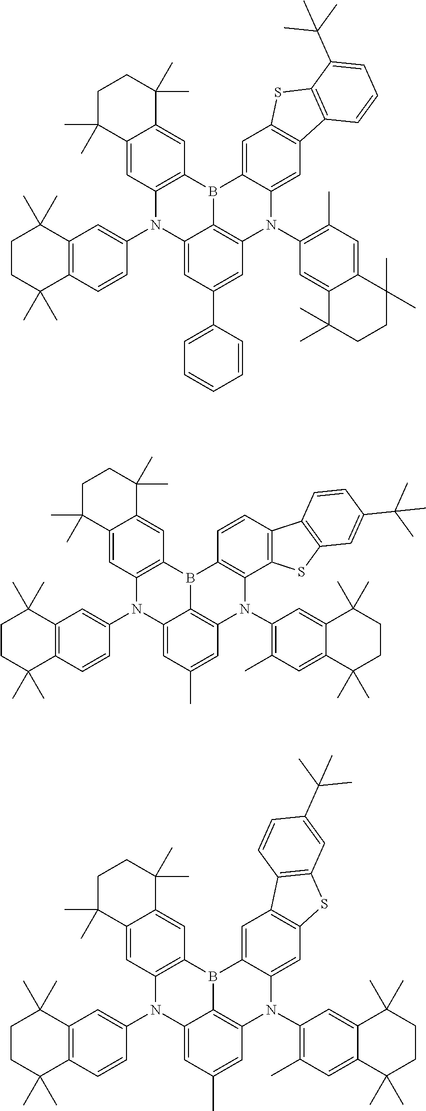 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)sc1c(C(C)(C)C)cccc14)C(C)(C)CCC2(C)C ; Cc1cc2c3c(c1)N(c1cc4c(cc1C)C(C)(C)CCC4(C)C)c1c(ccc4c1sc1cc(C(C)(C)C)ccc14)B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc4sc5cc(C(C)(C)C)ccc5c4cc1B3c1cc3c(cc1N2c1ccc2c(c1)C(C)(C)CCC2(C)C)C(C)(C)CCC3(C)C]

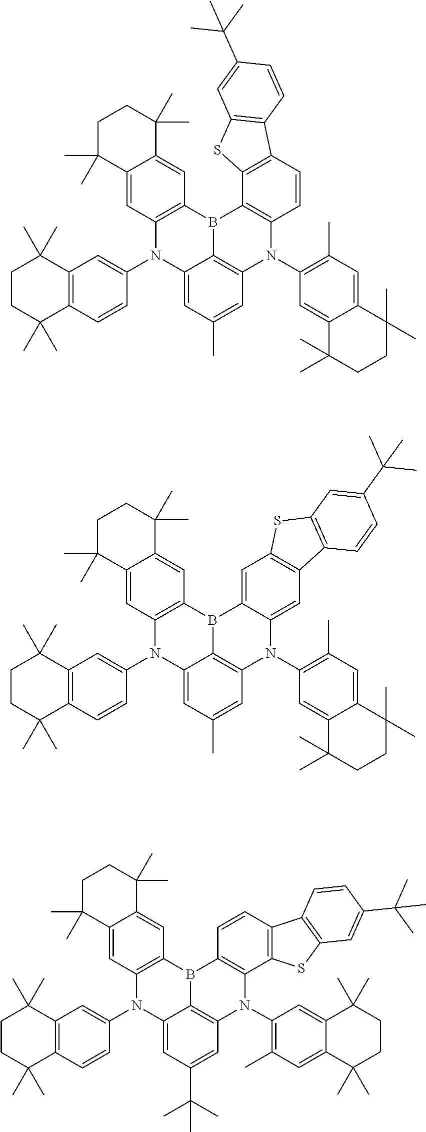 [SMILES: Cc1cc2c3c(c1)N(c1cc4c(cc1C)C(C)(C)CCC4(C)C)c1ccc4c(sc5cc(C(C)(C)C)ccc54)c1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1cc(C(C)(C)C)ccc14 ; Cc1cc2c(cc1N1c3cc(C(C)(C)C)cc4c3B(c3cc5c(cc3N4c3ccc4c(c3)C(C)(C)CCC4(C)C)C(C)(C)CCC5(C)C)c3ccc4c(sc5cc(C(C)(C)C)ccc54)c31)C(C)(C)CCC2(C)C]

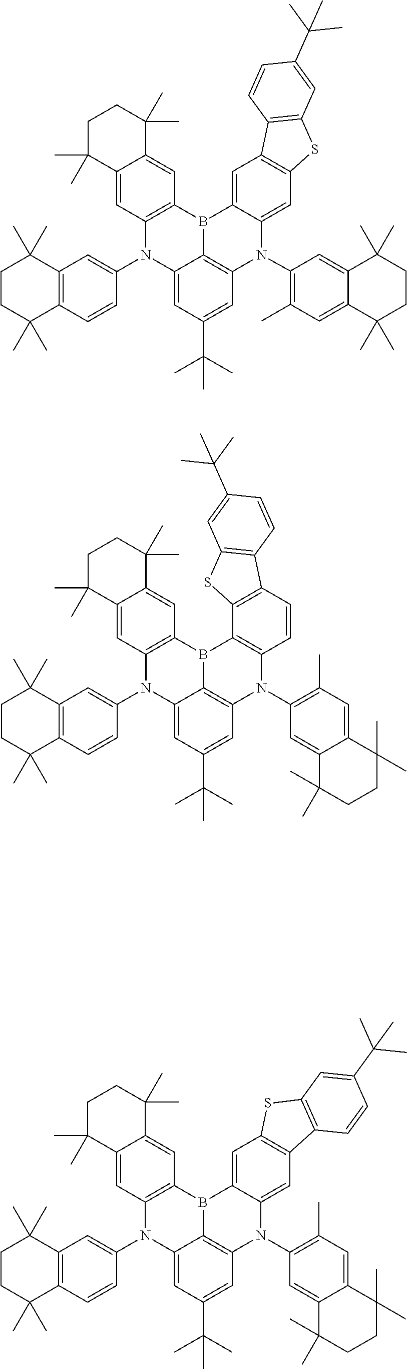

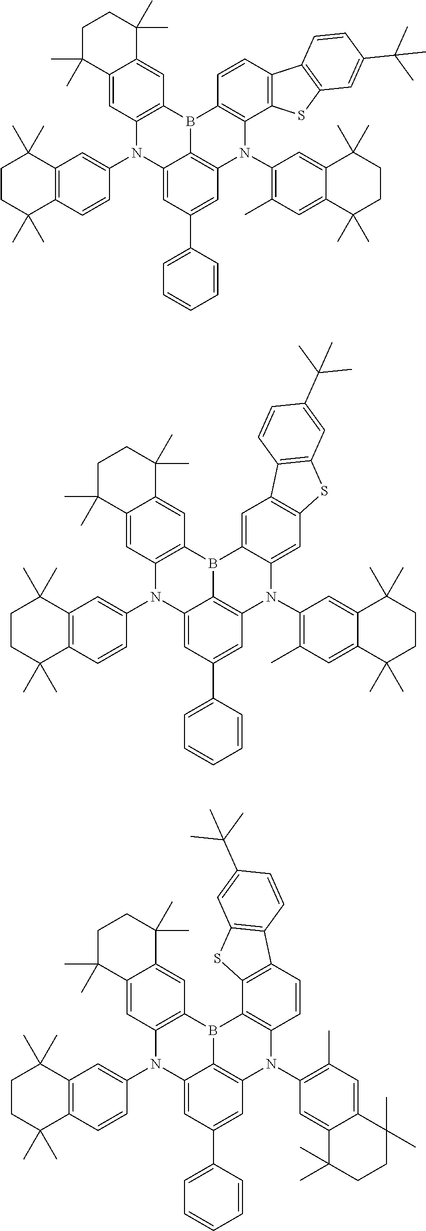

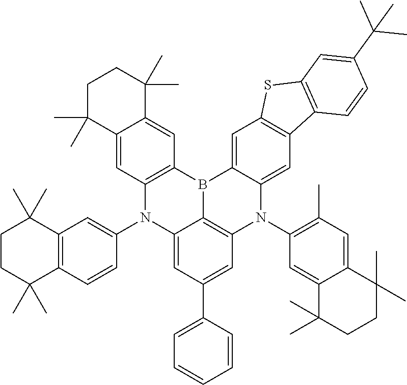 [SMILES: Cc1cc2c(cc1N1c3cc4c(cc3B3c5cc6c(cc5N(c5ccc7c(c5)C(C)(C)CCC7(C)C)c5cc(-c7ccccc7)cc1c53)C(C)(C)CCC6(C)C)sc1cc(C(C)(C)C)ccc14)C(C)(C)CCC2(C)C]

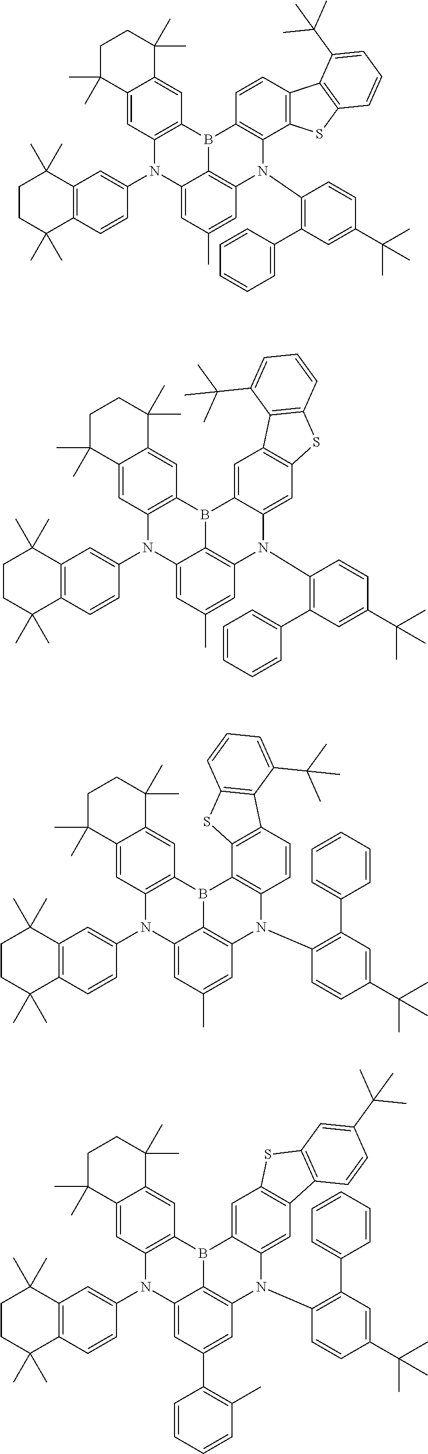

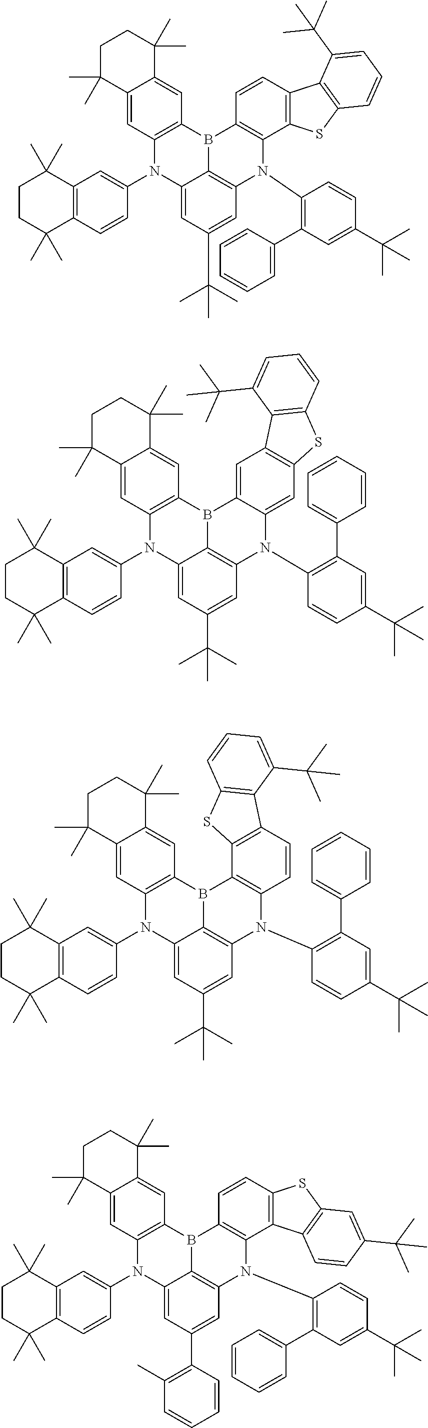

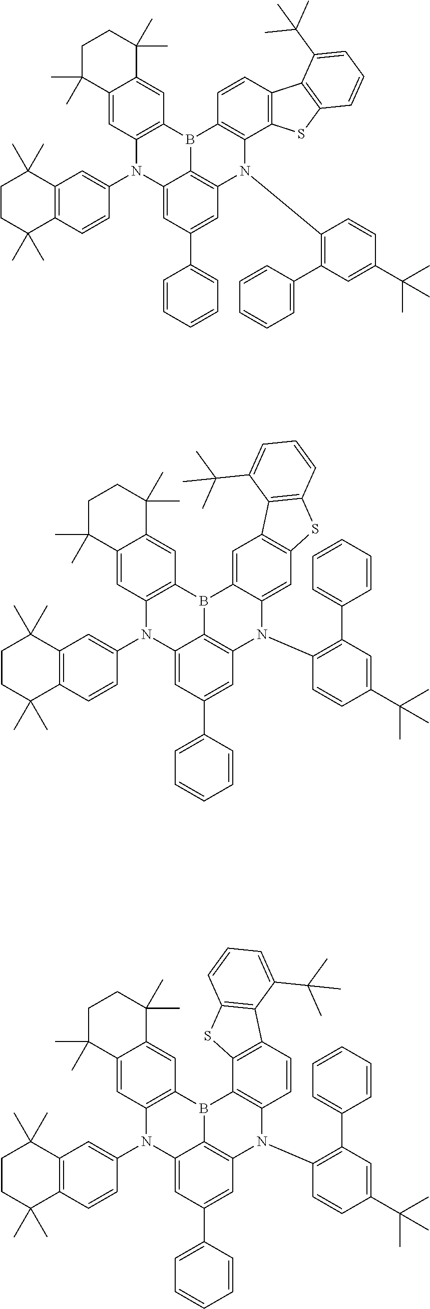 [SMILES: CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3ccc4c(sc5cccc(C(C)(C)C)c54)c32)c(-c2ccccc2)c1 ; CC(C)(C)c1ccc(N2c3cc4sc5cccc(C(C)(C)C)c5c4cc3B3c4cc5c(cc4N(c4ccc6c(c4)C(C)(C)CCC6(C)C)c4cc(-c6ccccc6)cc2c43)C(C)(C)CCC5(C)C)c(-c2ccccc2)c1 ; CC(C)(C)c1ccc(N2c3cc(-c4ccccc4)cc4c3B(c3cc5c(cc3N4c3ccc4c(c3)C(C)(C)CCC4(C)C)C(C)(C)CCC5(C)C)c3c2ccc2c3sc3cccc(C(C)(C)C)c32)c(-c2ccccc2)c1]

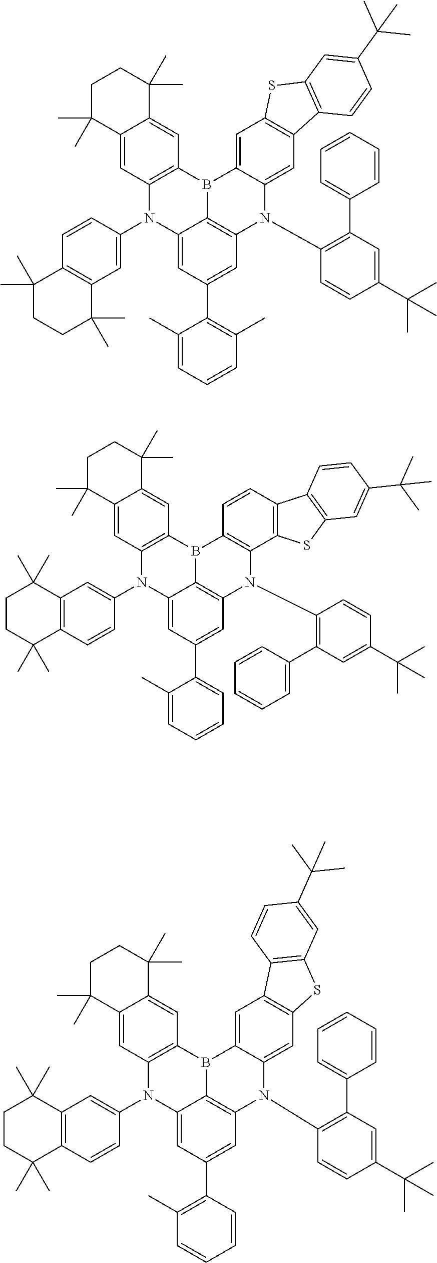 [SMILES: Cc1cccc(C)c1-c1cc2c3c(c1)N(c1ccc(C(C)(C)C)cc1-c1ccccc1)c1cc4c(cc1B3c1cc3c(cc1N2c1ccc2c(c1)C(C)(C)CCC2(C)C)C(C)(C)CCC3(C)C)sc1cc(C(C)(C)C)ccc14 ; Cc1ccccc1-c1cc2c3c(c1)N(c1ccc(C(C)(C)C)cc1-c1ccccc1)c1c(ccc4c1sc1cc(C(C)(C)C)ccc14)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1cc4sc5cc(C(C)(C)C)ccc5c4cc1B3c1cc3c(cc1N2c1ccc2c(c1)C(C)(C)CCC2(C)C)C(C)(C)CCC3(C)C]

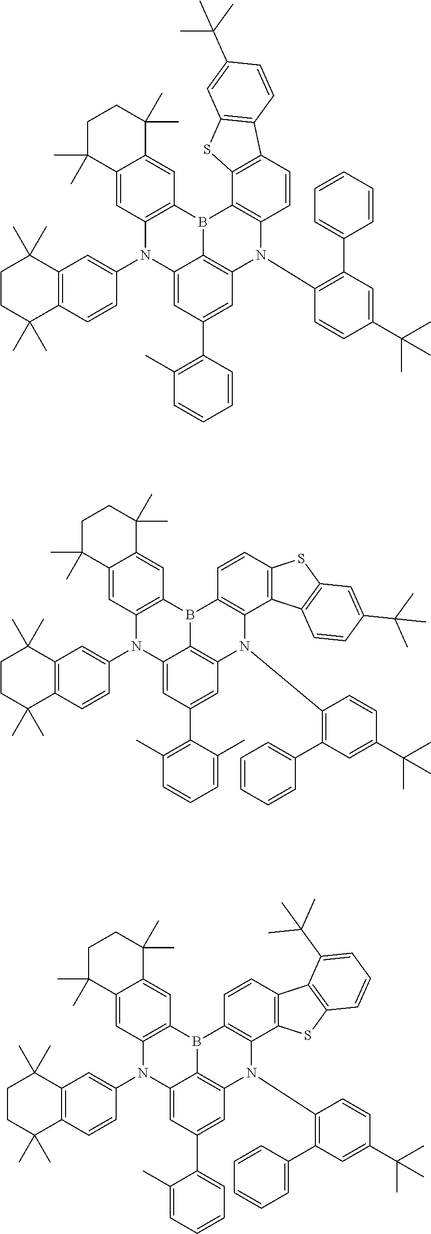 [SMILES: Cc1ccccc1-c1cc2c3c(c1)N(c1ccc(C(C)(C)C)cc1-c1ccccc1)c1ccc4c(sc5cc(C(C)(C)C)ccc54)c1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1c(ccc4sc5cc(C(C)(C)C)ccc5c14)B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1c(ccc4c1sc1cccc(C(C)(C)C)c14)B3c1cc3c(cc1N2c1ccc2c(c1)C(C)(C)CCC2(C)C)C(C)(C)CCC3(C)C]

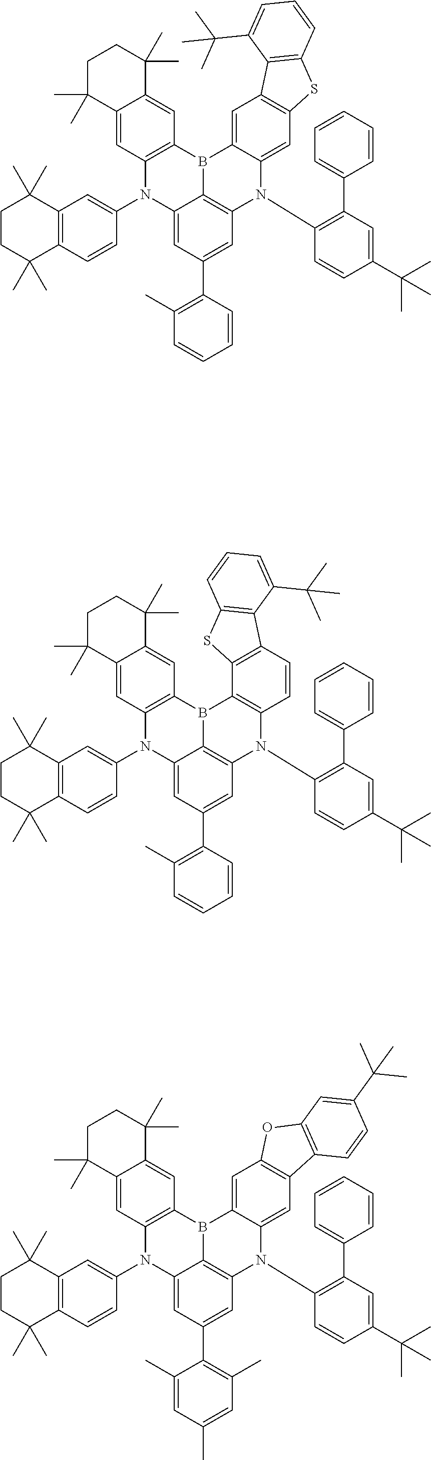 [SMILES: Cc1ccccc1-c1cc2c3c(c1)N(c1ccc(C(C)(C)C)cc1-c1ccccc1)c1cc4sc5cccc(C(C)(C)C)c5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1ccc(C(C)(C)C)cc1-c1ccccc1)c1ccc4c(sc5cccc(C(C)(C)C)c54)c1B3c1cc3c(cc1N2c1ccc2c(c1)C(C)(C)CCC2(C)C)C(C)(C)CCC3(C)C ; Cc1cc(C)c(-c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2cc(C(C)(C)C)ccc25)c(C)c1]

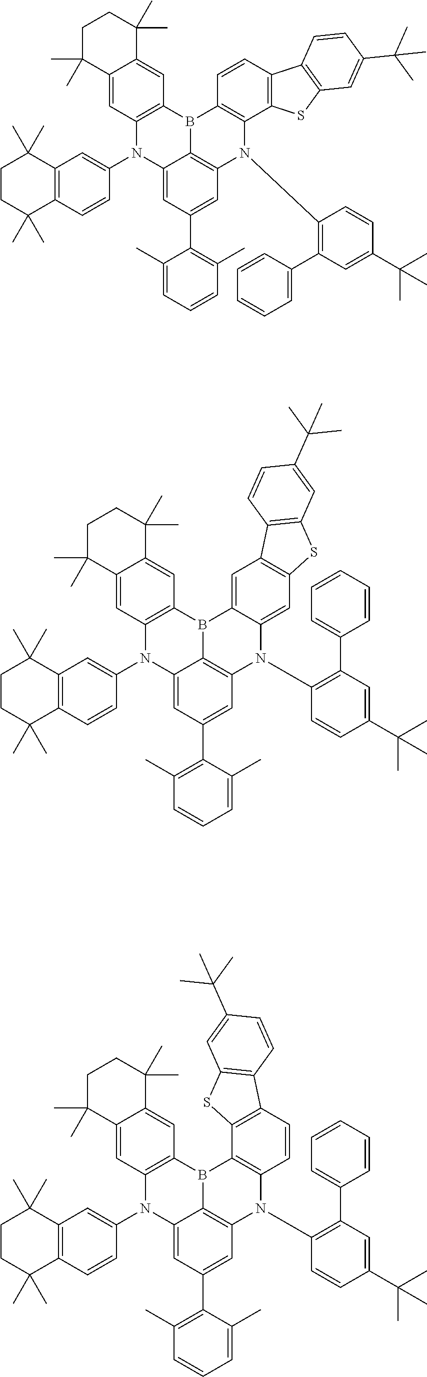 [SMILES: Cc1cccc(C)c1-c1cc2c3c(c1)N(c1ccc(C(C)(C)C)cc1-c1ccccc1)c1c(ccc4c1sc1cc(C(C)(C)C)ccc14)B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1cc4sc5cc(C(C)(C)C)ccc5c4cc1B3c1cc3c(cc1N2c1ccc2c(c1)C(C)(C)CCC2(C)C)C(C)(C)CCC3(C)C ; Cc1cccc(C)c1-c1cc2c3c(c1)N(c1ccc(C(C)(C)C)cc1-c1ccccc1)c1ccc4c(sc5cc(C(C)(C)C)ccc54)c1B3c1cc3c(cc1N2c1ccc2c(c1)C(C)(C)CCC2(C)C)C(C)(C)CCC3(C)C]

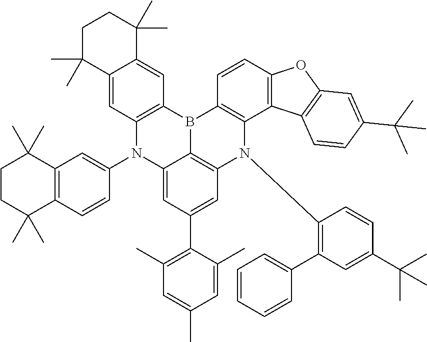 [SMILES: Cc1cc(C)c(-c2cc3c4c(c2)N(c2ccc(C(C)(C)C)cc2-c2ccccc2)c2c(ccc5oc6cc(C(C)(C)C)ccc6c25)B4c2cc4c(cc2N3c2ccc3c(c2)C(C)(C)CCC3(C)C)C(C)(C)CCC4(C)C)c(C)c1]

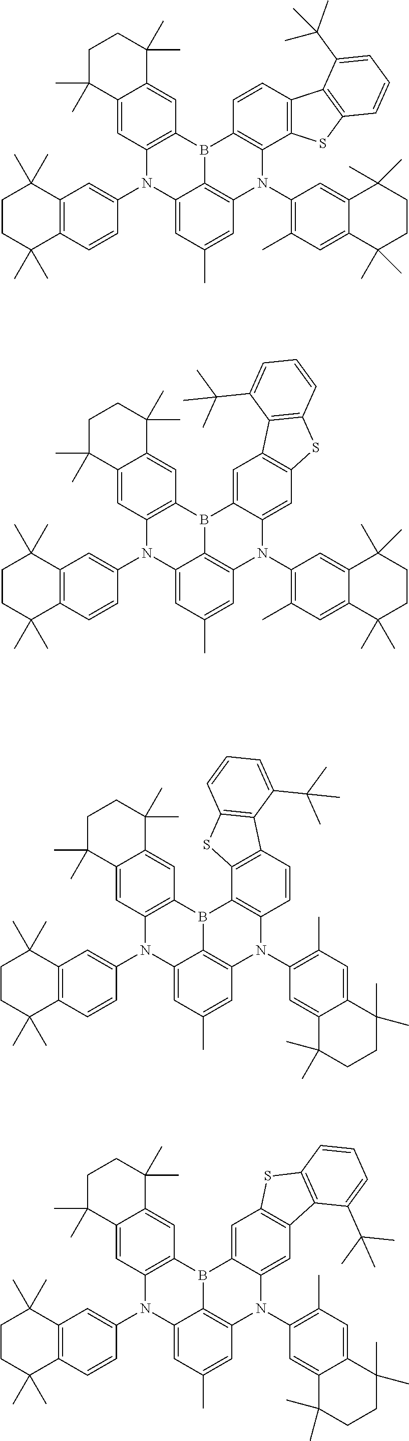

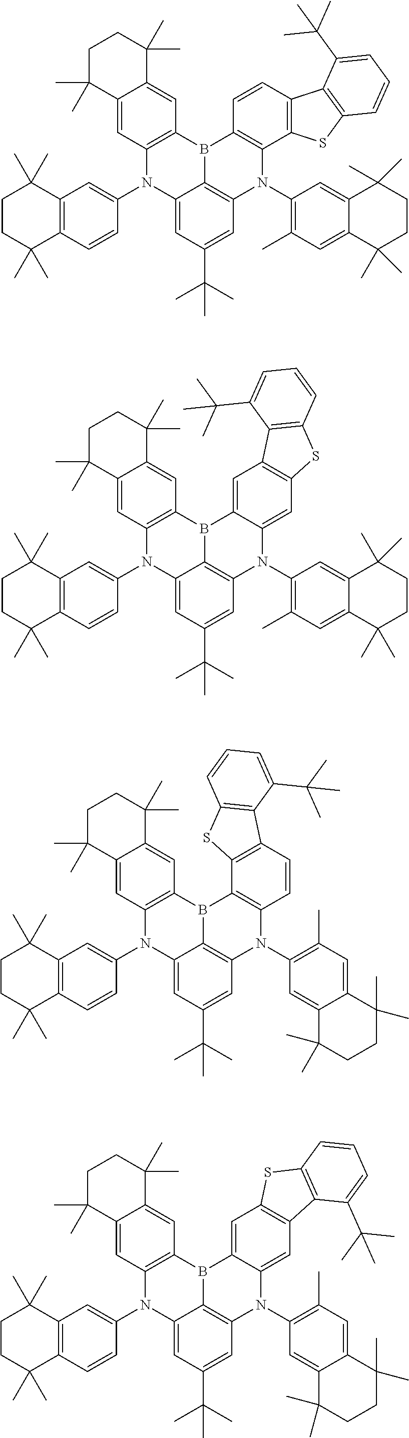

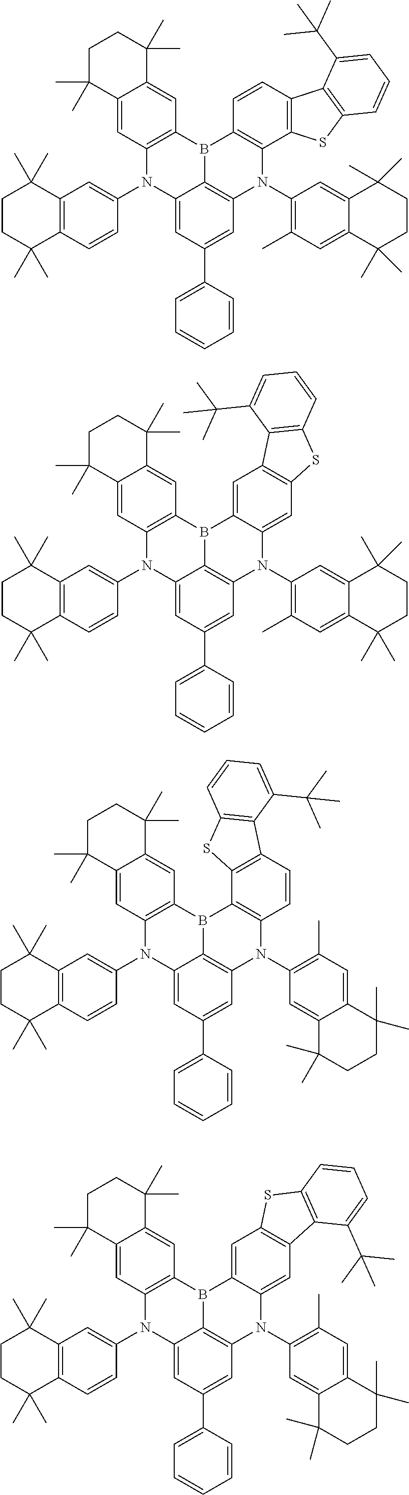

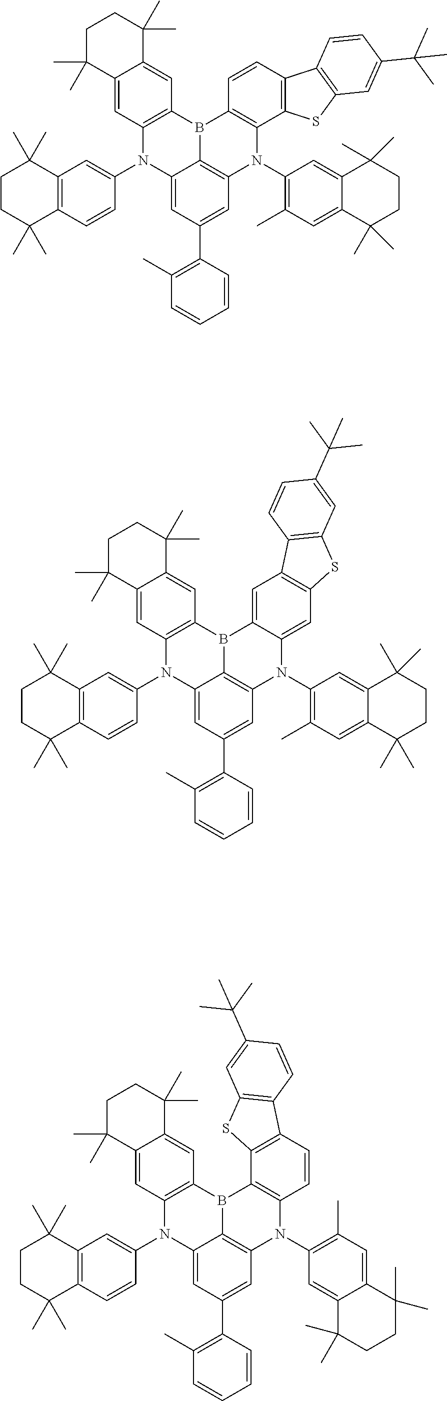 [SMILES: Cc1ccccc1-c1cc2c3c(c1)N(c1cc4c(cc1C)C(C)(C)CCC4(C)C)c1c(ccc4c1sc1cc(C(C)(C)C)ccc14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4sc5cc(C(C)(C)C)ccc5c4cc1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1ccc4c(sc5cc(C(C)(C)C)ccc54)c1B3c1cc3c(cc1N2c1ccc2c(c1)C(C)(C)CCC2(C)C)C(C)(C)CCC3(C)C]

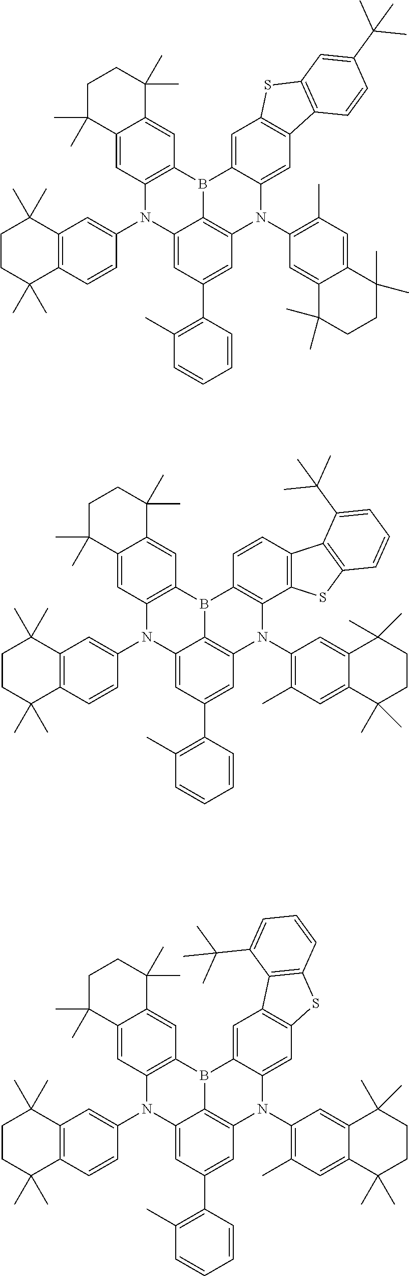 [SMILES: Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1cc(C(C)(C)C)ccc14 ; Cc1ccccc1-c1cc2c3c(c1)N(c1cc4c(cc1C)C(C)(C)CCC4(C)C)c1c(ccc4c1sc1cccc(C(C)(C)C)c14)B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4sc5cccc(C(C)(C)C)c5c4cc1B3c1cc3c(cc1N2c1ccc2c(c1)C(C)(C)CCC2(C)C)C(C)(C)CCC3(C)C]

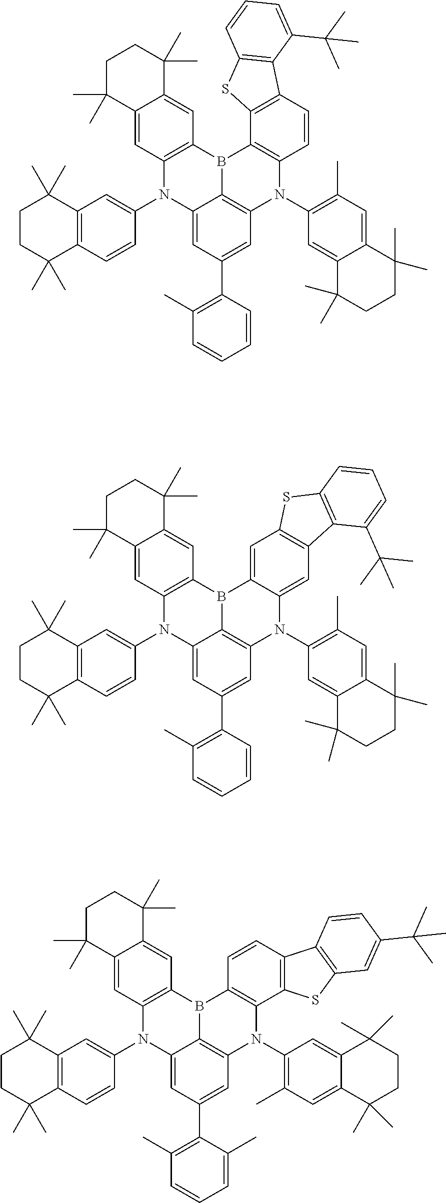 [SMILES: Cc1ccccc1-c1cc2c3c(c1)N(c1cc4c(cc1C)C(C)(C)CCC4(C)C)c1ccc4c(sc5cccc(C(C)(C)C)c54)c1B3c1cc3c(cc1N2c1ccc2c(c1)C(C)(C)CCC2(C)C)C(C)(C)CCC3(C)C ; Cc1ccccc1-c1cc2c3c(c1)N(c1cc4c(cc1C)C(C)(C)CCC4(C)C)c1cc4c(cc1B3c1cc3c(cc1N2c1ccc2c(c1)C(C)(C)CCC2(C)C)C(C)(C)CCC3(C)C)sc1cccc(C(C)(C)C)c14 ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5cc(C(C)(C)C)ccc54)c31)C(C)(C)CCC2(C)C]

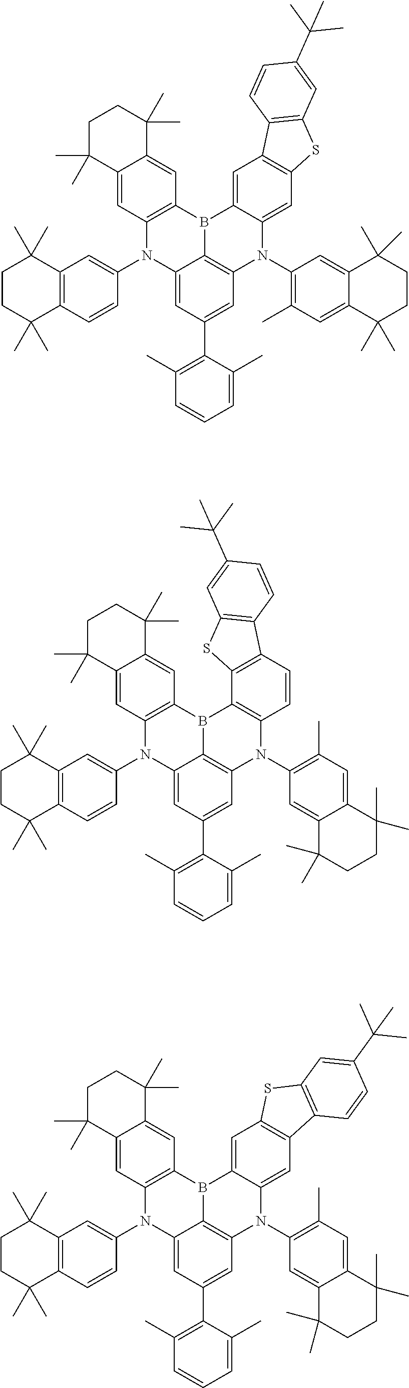 [SMILES: Cc1cc2c(cc1N1c3cc4sc5cc(C(C)(C)C)ccc5c4cc3B3c4cc5c(cc4N(c4ccc6c(c4)C(C)(C)CCC6(C)C)c4cc(-c6c(C)cccc6C)cc1c43)C(C)(C)CCC5(C)C)C(C)(C)CCC2(C)C ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3c1ccc1c3sc3cc(C(C)(C)C)ccc31)C(C)(C)CCC2(C)C ; Cc1cc2c(cc1N1c3cc4c(cc3B3c5cc6c(cc5N(c5ccc7c(c5)C(C)(C)CCC7(C)C)c5cc(-c7c(C)cccc7C)cc1c53)C(C)(C)CCC6(C)C)sc1cc(C(C)(C)C)ccc14)C(C)(C)CCC2(C)C]

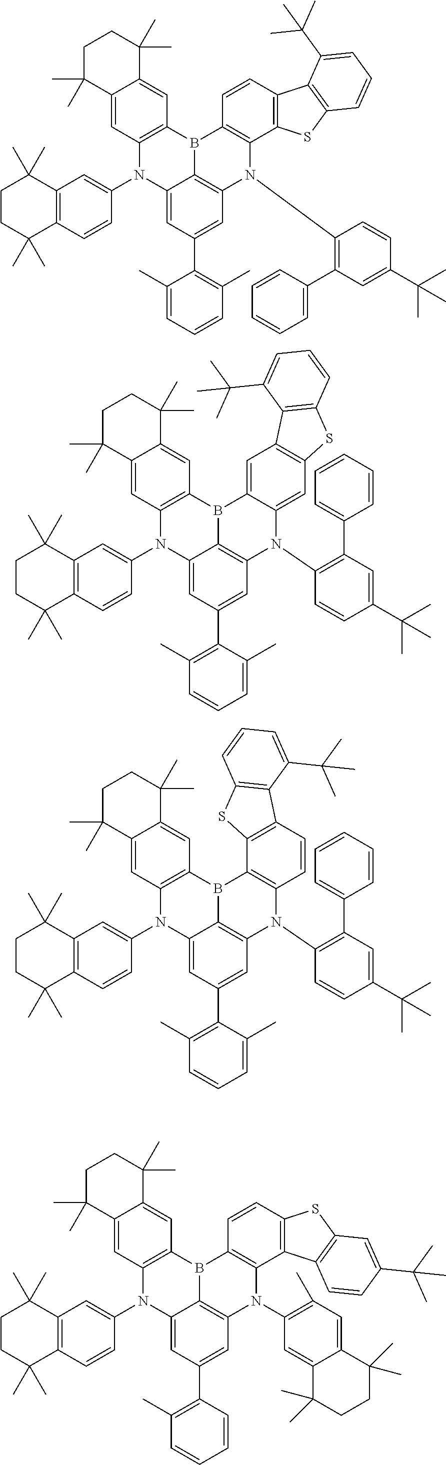

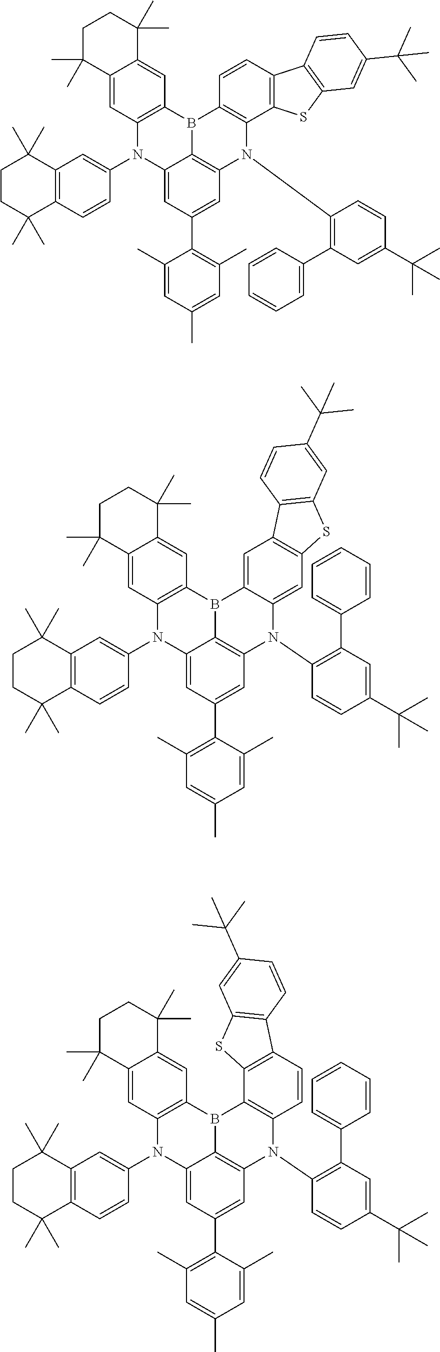 [SMILES: Cc1cc(C)c(-c2cc3c4c(c2)N(c2ccc(C(C)(C)C)cc2-c2ccccc2)c2c(ccc5c2sc2cc(C(C)(C)C)ccc25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6cc(C(C)(C)C)ccc6c5cc2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2ccc5c(sc6cc(C(C)(C)C)ccc65)c2B4c2cc4c(cc2N3c2ccc3c(c2)C(C)(C)CCC3(C)C)C(C)(C)CCC4(C)C)c(C)c1]

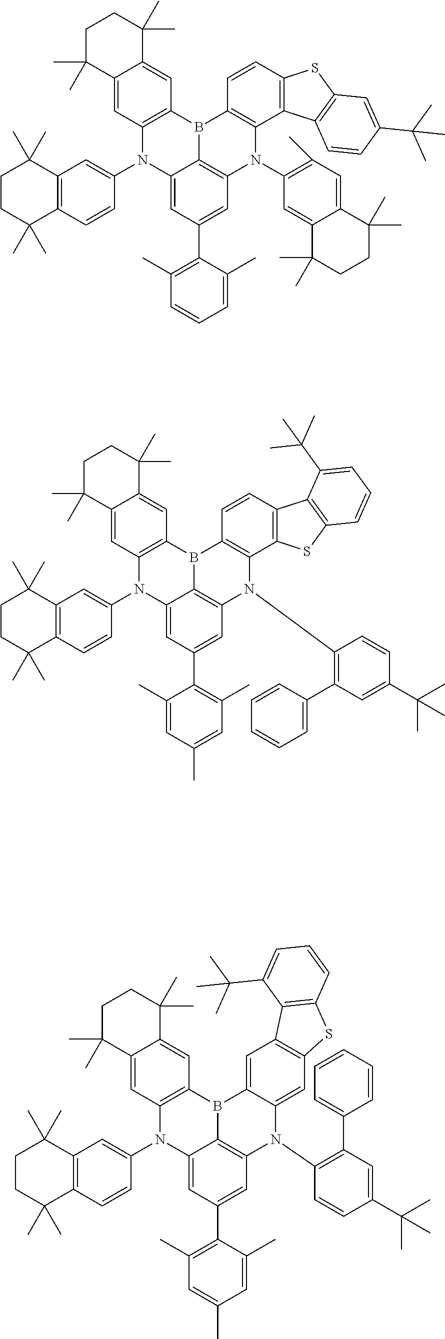 [SMILES: Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4sc5cc(C(C)(C)C)ccc5c4c31)C(C)(C)CCC2(C)C ; Cc1cc(C)c(-c2cc3c4c(c2)N(c2ccc(C(C)(C)C)cc2-c2ccccc2)c2c(ccc5c2sc2cccc(C(C)(C)C)c25)B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2ccc(C(C)(C)C)cc2-c2ccccc2)c2cc5sc6cccc(C(C)(C)C)c6c5cc2B4c2cc4c(cc2N3c2ccc3c(c2)C(C)(C)CCC3(C)C)C(C)(C)CCC4(C)C)c(C)c1]

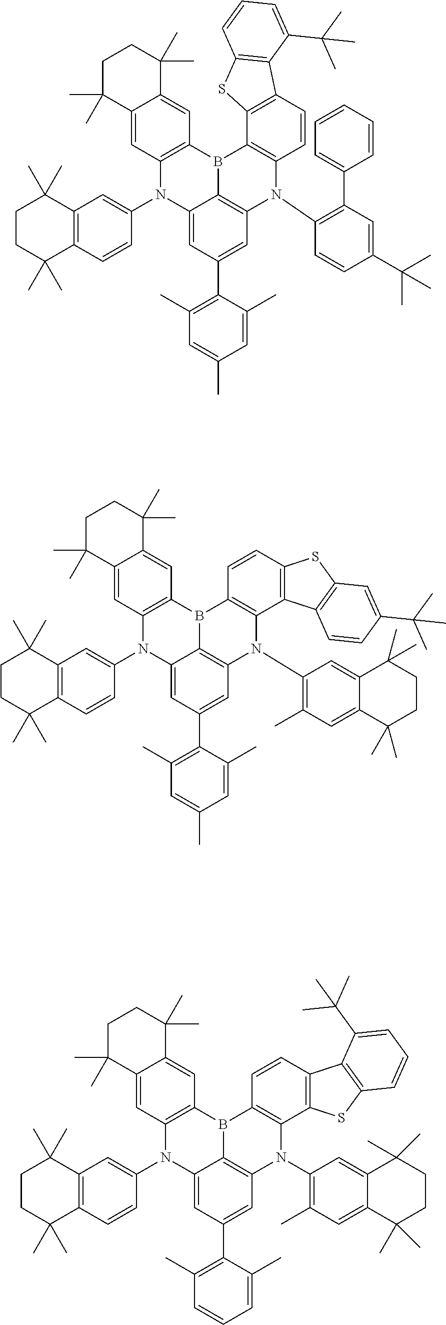 [SMILES: Cc1cc(C)c(-c2cc3c4c(c2)N(c2ccc(C(C)(C)C)cc2-c2ccccc2)c2ccc5c(sc6cccc(C(C)(C)C)c65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2c(ccc5sc6cc(C(C)(C)C)ccc6c25)B4c2cc4c(cc2N3c2ccc3c(c2)C(C)(C)CCC3(C)C)C(C)(C)CCC4(C)C)c(C)c1 ; Cc1cc2c(cc1N1c3cc(-c4c(C)cccc4C)cc4c3B(c3cc5c(cc3N4c3ccc4c(c3)C(C)(C)CCC4(C)C)C(C)(C)CCC5(C)C)c3ccc4c(sc5cccc(C(C)(C)C)c54)c31)C(C)(C)CCC2(C)C]

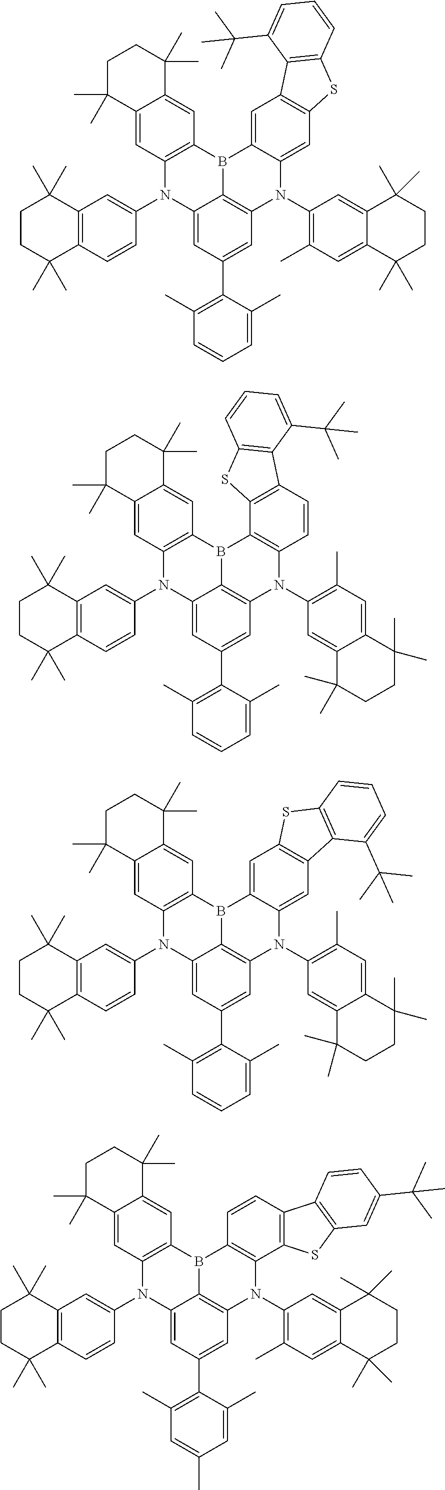

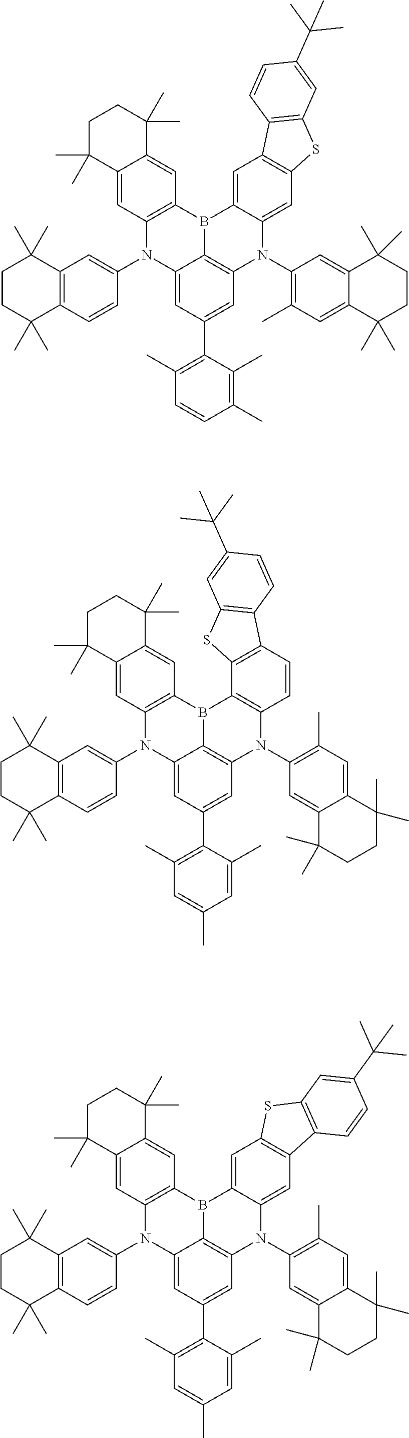 [SMILES: Cc1cc2c(cc1N1c3cc4sc5cc(C(C)(C)C)ccc5c4cc3B3c4cc5c(cc4N(c4ccc6c(c4)C(C)(C)CCC6(C)C)c4cc(-c6c(C)ccc(C)c6C)cc1c43)C(C)(C)CCC5(C)C)C(C)(C)CCC2(C)C ; Cc1cc(C)c(-c2cc3c4c(c2)N(c2cc5c(cc2C)C(C)(C)CCC5(C)C)c2ccc5c(sc6cc(C(C)(C)C)ccc65)c2B4c2cc4c(cc2N3c2ccc3c(c2)C(C)(C)CCC3(C)C)C(C)(C)CCC4(C)C)c(C)c1 ; Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2cc(C(C)(C)C)ccc25)c(C)c1]

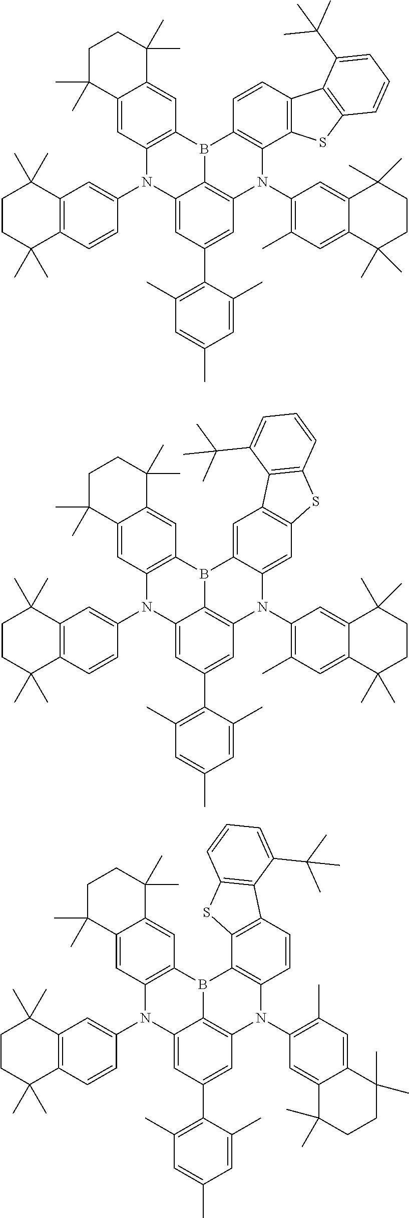

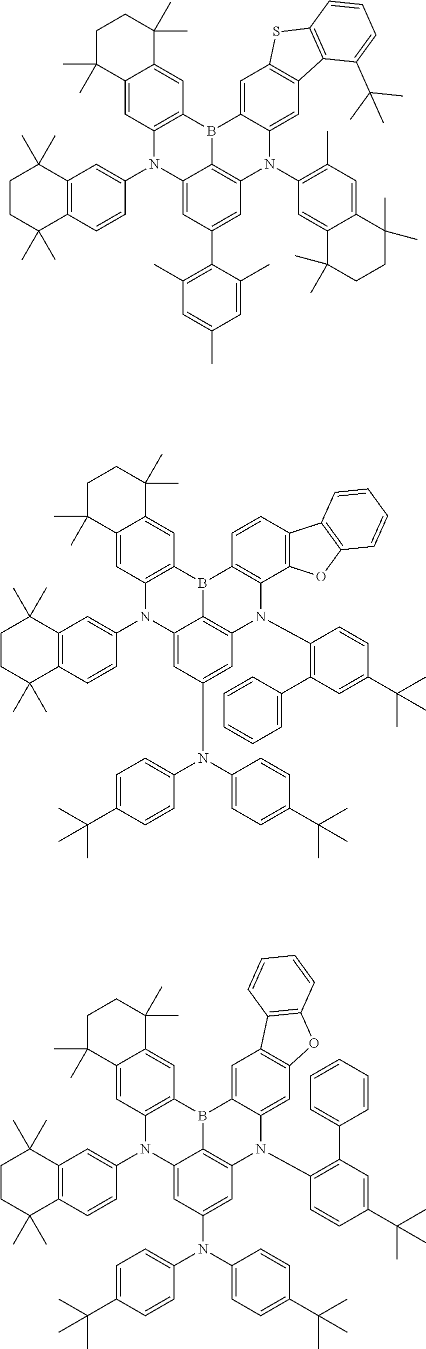 [SMILES: Cc1cc(C)c(-c2cc3c4c(c2)N(c2cc5c(cc2C)C(C)(C)CCC5(C)C)c2cc5c(cc2B4c2cc4c(cc2N3c2ccc3c(c2)C(C)(C)CCC3(C)C)C(C)(C)CCC4(C)C)sc2cccc(C(C)(C)C)c25)c(C)c1 ; CC(C)(C)c1ccc(N(c2ccc(C(C)(C)C)cc2)c2cc3c4c(c2)N(c2ccc(C(C)(C)C)cc2-c2ccccc2)c2c(ccc5c2oc2ccccc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5oc6ccccc6c5cc2B4c2cc4c(cc2N3c2ccc3c(c2)C(C)(C)CCC3(C)C)C(C)(C)CCC4(C)C)cc1]

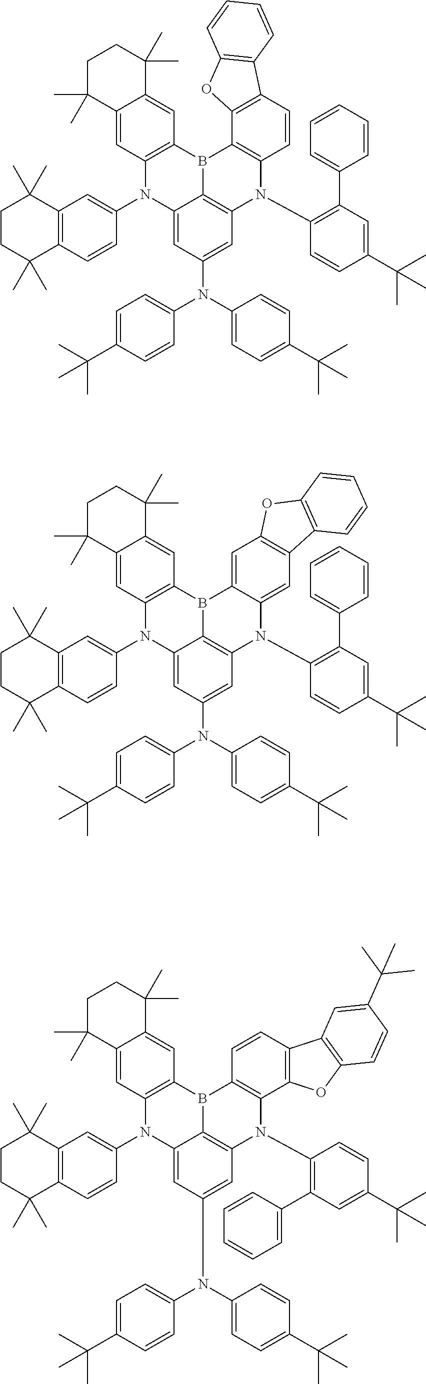 [SMILES: CC(C)(C)c1ccc(N(c2ccc(C(C)(C)C)cc2)c2cc3c4c(c2)N(c2ccc(C(C)(C)C)cc2-c2ccccc2)c2ccc5c(oc6ccccc65)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2ccccc25)cc1 ; CC(C)(C)c1ccc(N(c2ccc(C(C)(C)C)cc2)c2cc3c4c(c2)N(c2ccc(C(C)(C)C)cc2-c2ccccc2)c2c(ccc5c2oc2ccc(C(C)(C)C)cc25)B4c2cc4c(cc2N3c2ccc3c(c2)C(C)(C)CCC3(C)C)C(C)(C)CCC4(C)C)cc1]

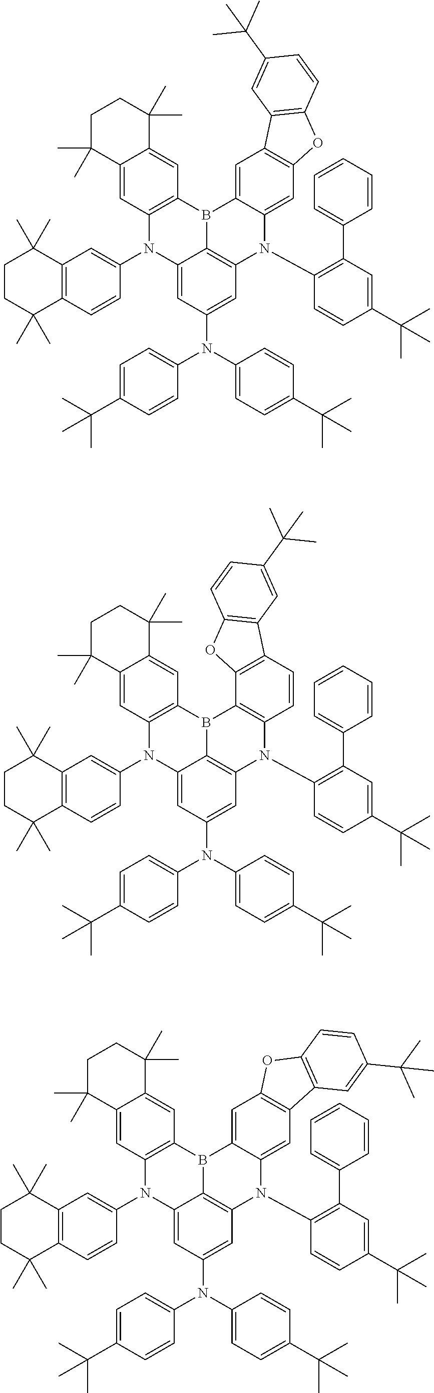

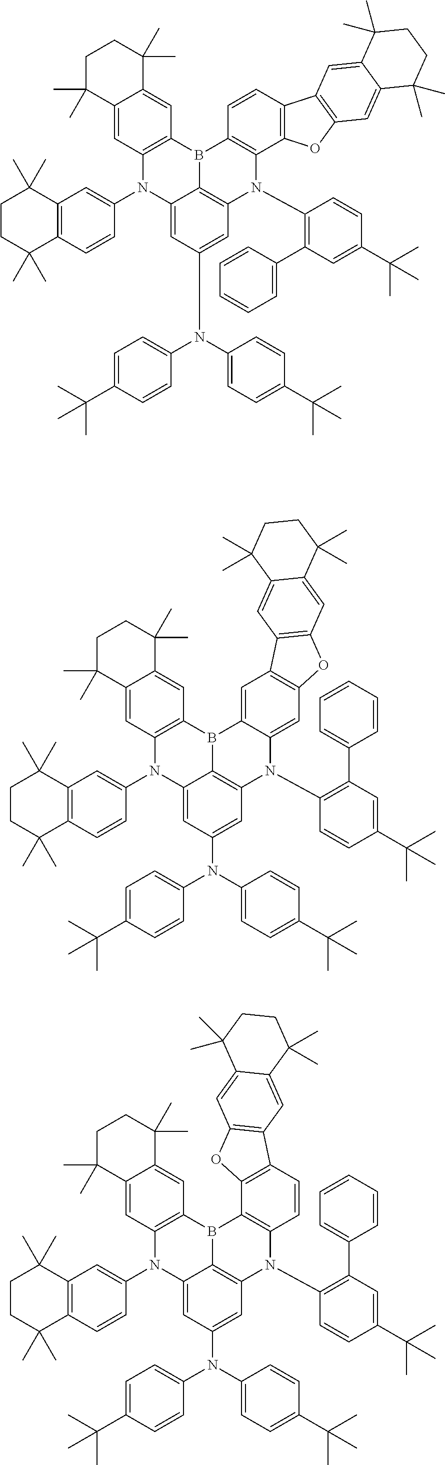

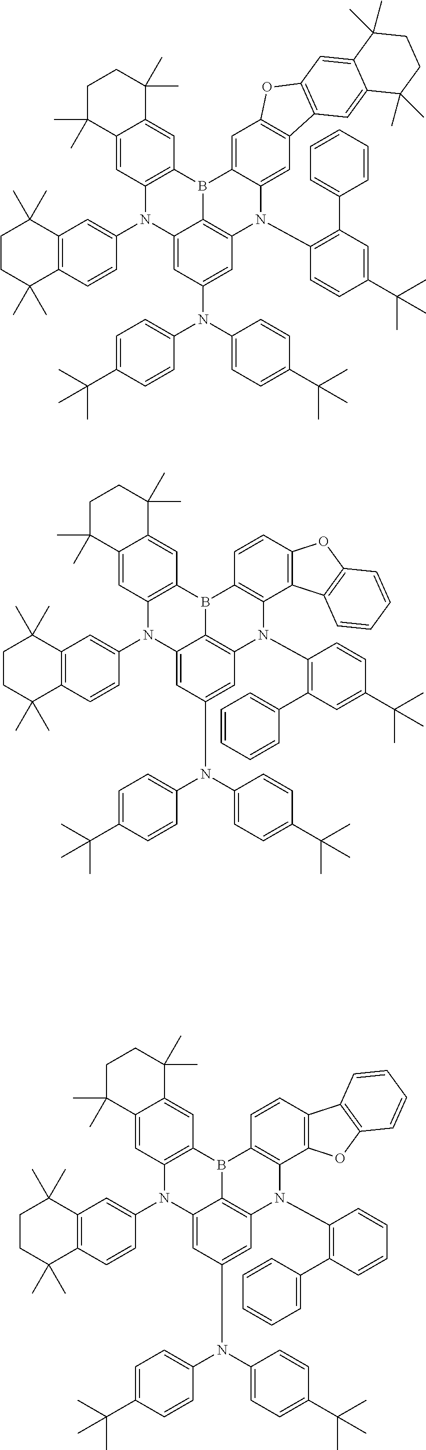 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)cc1 ; CC(C)(C)c1ccc(N(c2ccc(C(C)(C)C)cc2)c2cc3c4c(c2)N(c2ccc(C(C)(C)C)cc2-c2ccccc2)c2c(ccc5oc6ccccc6c25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2c(ccc5c2oc2ccccc25)B4c2cc4c(cc2N3c2ccc3c(c2)C(C)(C)CCC3(C)C)C(C)(C)CCC4(C)C)cc1]

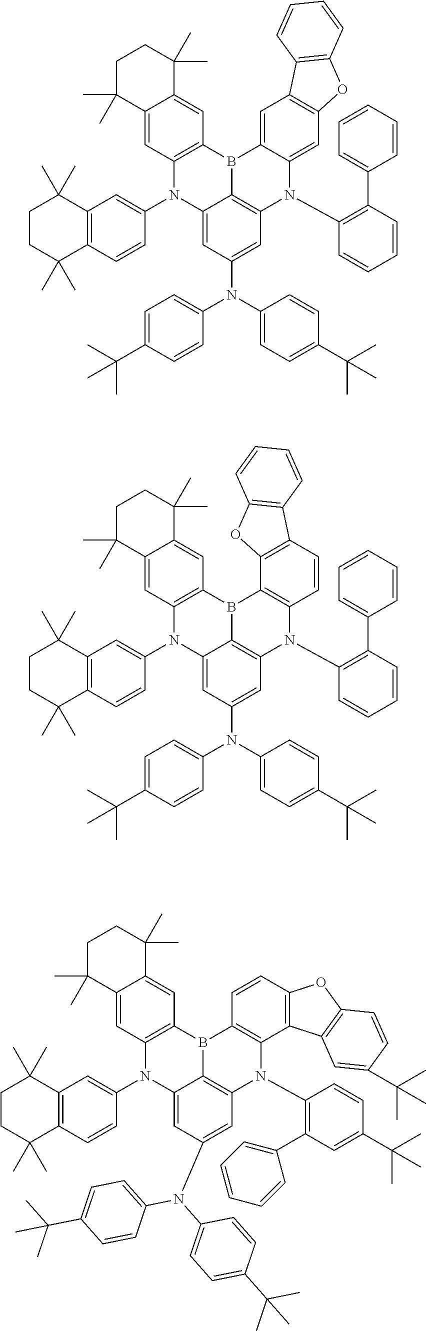 [SMILES: CC(C)(C)c1ccc(N(c2ccc(C(C)(C)C)cc2)c2cc3c4c(c2)N(c2ccccc2-c2ccccc2)c2cc5oc6ccccc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2ccc5c(oc6ccccc65)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2c(ccc5oc6ccc(C(C)(C)C)cc6c25)B4c2cc4c(cc2N3c2ccc3c(c2)C(C)(C)CCC3(C)C)C(C)(C)CCC4(C)C)cc1]

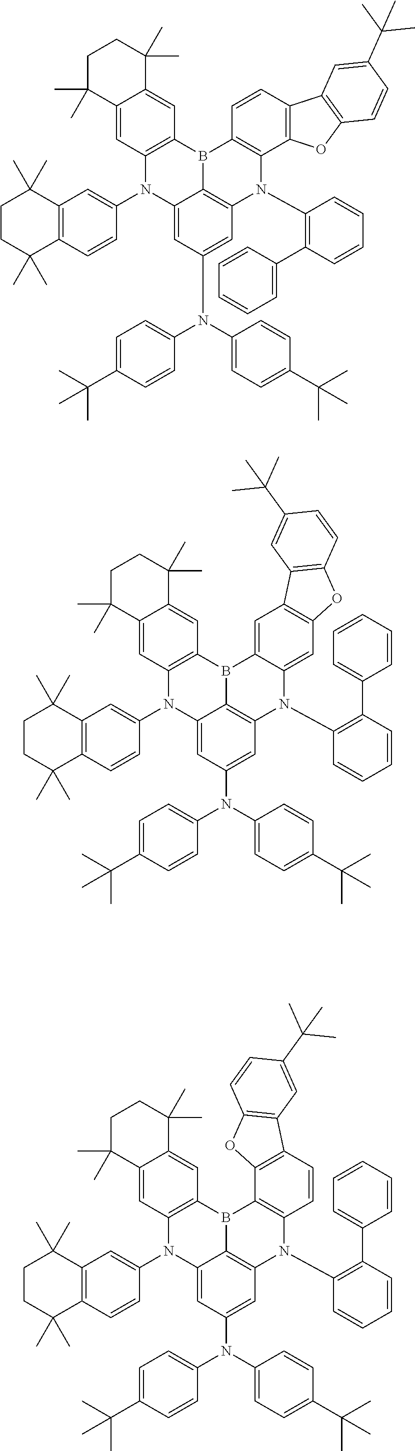 [SMILES: CC(C)(C)c1ccc(N(c2ccc(C(C)(C)C)cc2)c2cc3c4c(c2)N(c2ccccc2-c2ccccc2)c2c(ccc5c2oc2ccc(C(C)(C)C)cc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5oc6ccc(C(C)(C)C)cc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2ccc5c(oc6ccc(C(C)(C)C)cc65)c2B4c2cc4c(cc2N3c2ccc3c(c2)C(C)(C)CCC3(C)C)C(C)(C)CCC4(C)C)cc1]

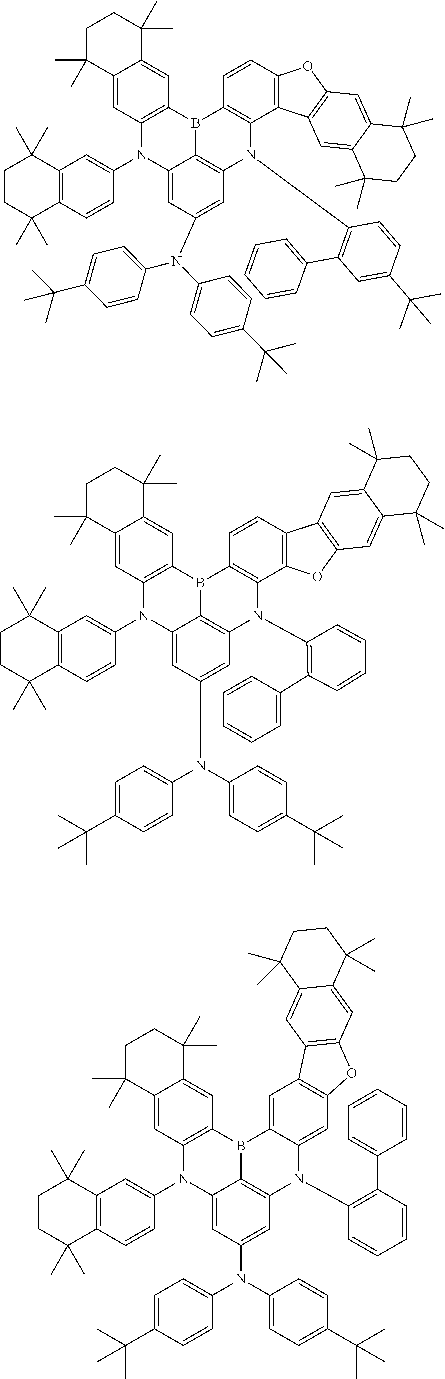

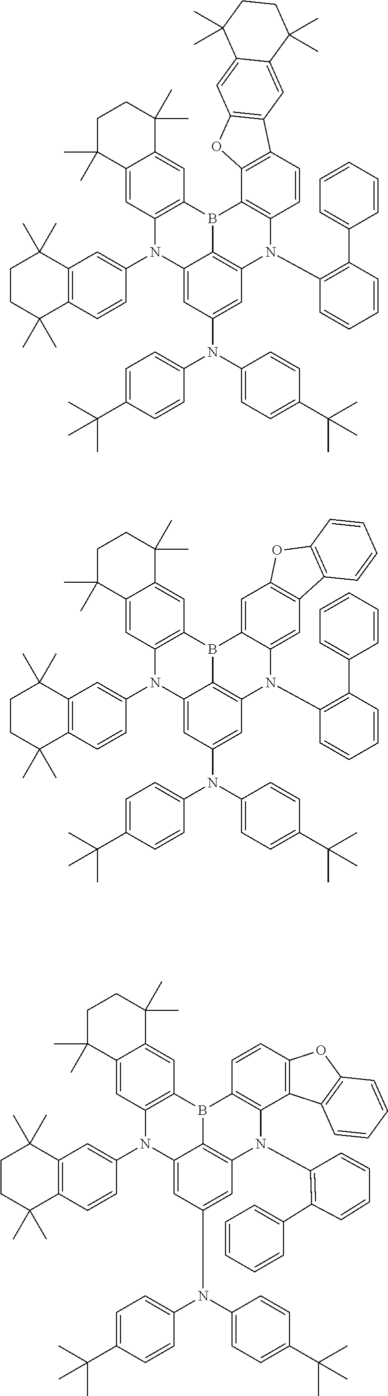 [SMILES: CC(C)(C)c1ccc(N(c2ccc(C(C)(C)C)cc2)c2cc3c4c(c2)N(c2ccccc2-c2ccccc2)c2ccc5c(oc6cc7c(cc65)C(C)(C)CCC7(C)C)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2ccccc25)cc1 ; CC(C)(C)c1ccc(N(c2ccc(C(C)(C)C)cc2)c2cc3c4c(c2)N(c2ccccc2-c2ccccc2)c2c(ccc5oc6ccccc6c25)B4c2cc4c(cc2N3c2ccc3c(c2)C(C)(C)CCC3(C)C)C(C)(C)CCC4(C)C)cc1]

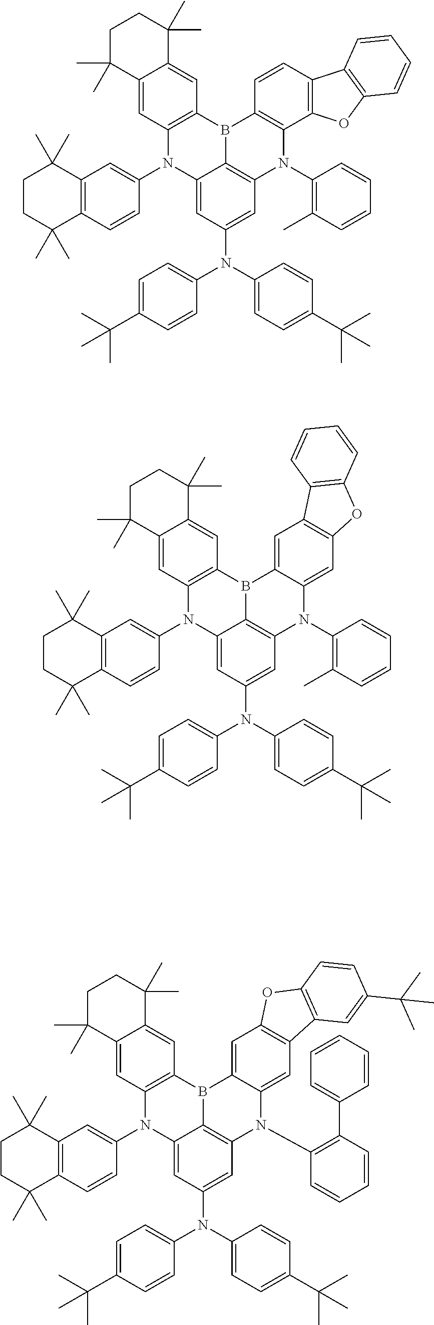 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(oc4ccccc43)c21 ; Cc1ccccc1N1c2cc3oc4ccccc4c3cc2B2c3cc4c(cc3N(c3ccc5c(c3)C(C)(C)CCC5(C)C)c3cc(N(c5ccc(C(C)(C)C)cc5)c5ccc(C(C)(C)C)cc5)cc1c32)C(C)(C)CCC4(C)C ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2ccc(C(C)(C)C)cc25)cc1]

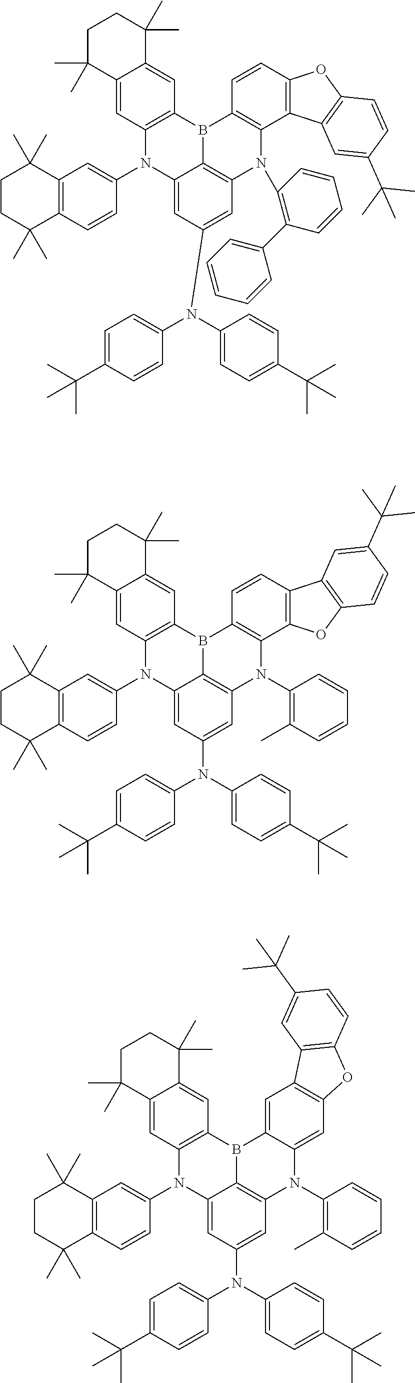 [SMILES: CC(C)(C)c1ccc(N(c2ccc(C(C)(C)C)cc2)c2cc3c4c(c2)N(c2ccccc2-c2ccccc2)c2c(ccc5oc6ccc(C(C)(C)C)cc6c25)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(oc4ccc(C(C)(C)C)cc43)c21 ; Cc1ccccc1N1c2cc3oc4ccc(C(C)(C)C)cc4c3cc2B2c3cc4c(cc3N(c3ccc5c(c3)C(C)(C)CCC5(C)C)c3cc(N(c5ccc(C(C)(C)C)cc5)c5ccc(C(C)(C)C)cc5)cc1c32)C(C)(C)CCC4(C)C]

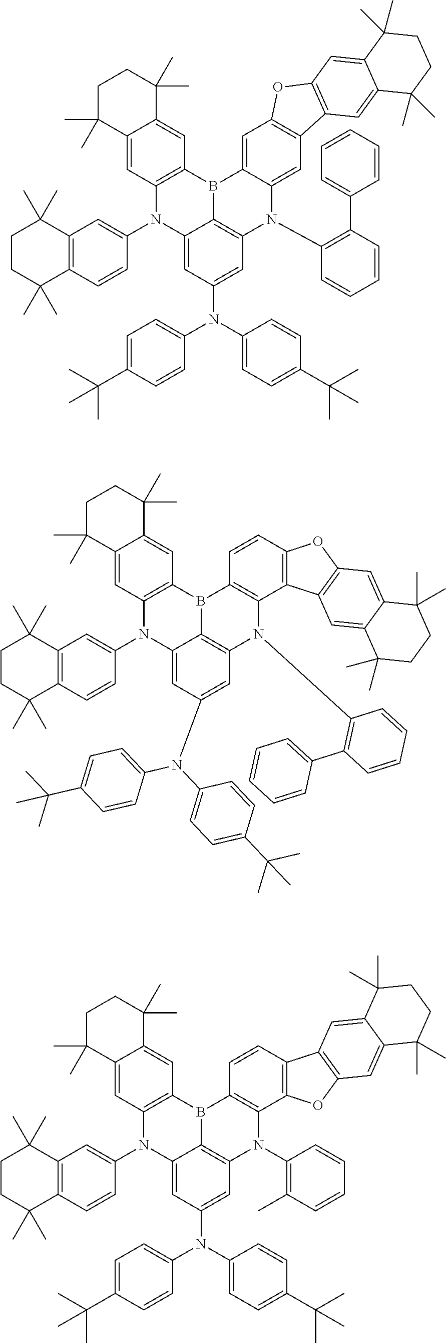 [SMILES: CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)oc2cc3c(cc25)C(C)(C)CCC3(C)C)cc1 ; CC(C)(C)c1ccc(N(c2ccc(C(C)(C)C)cc2)c2cc3c4c(c2)N(c2ccccc2-c2ccccc2)c2c(ccc5oc6cc7c(cc6c25)C(C)(C)CCC7(C)C)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(oc4cc5c(cc43)C(C)(C)CCC5(C)C)c21]

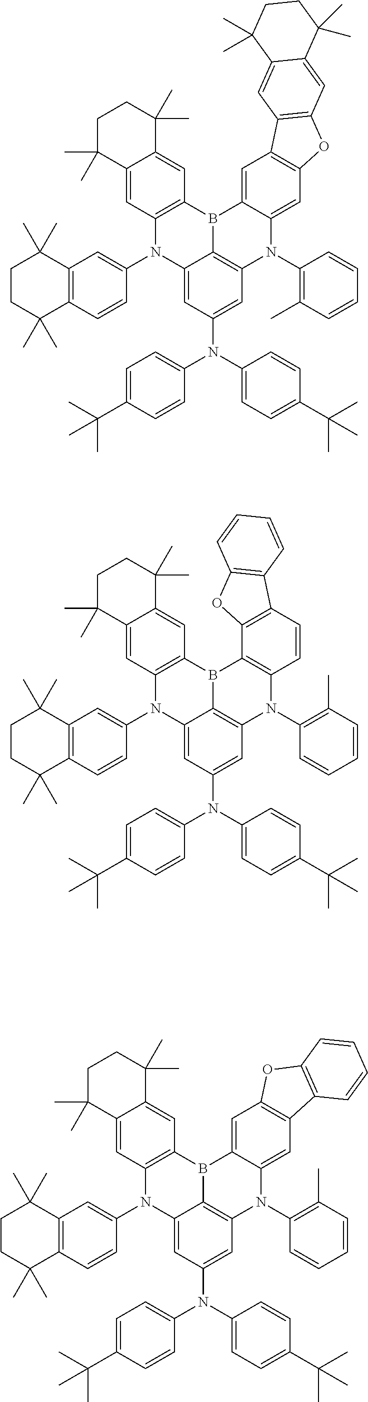 [SMILES: Cc1ccccc1N1c2cc3oc4cc5c(cc4c3cc2B2c3cc4c(cc3N(c3ccc6c(c3)C(C)(C)CCC6(C)C)c3cc(N(c6ccc(C(C)(C)C)cc6)c6ccc(C(C)(C)C)cc6)cc1c32)C(C)(C)CCC4(C)C)C(C)(C)CCC5(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2oc2ccccc21 ; Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)oc1ccccc13]

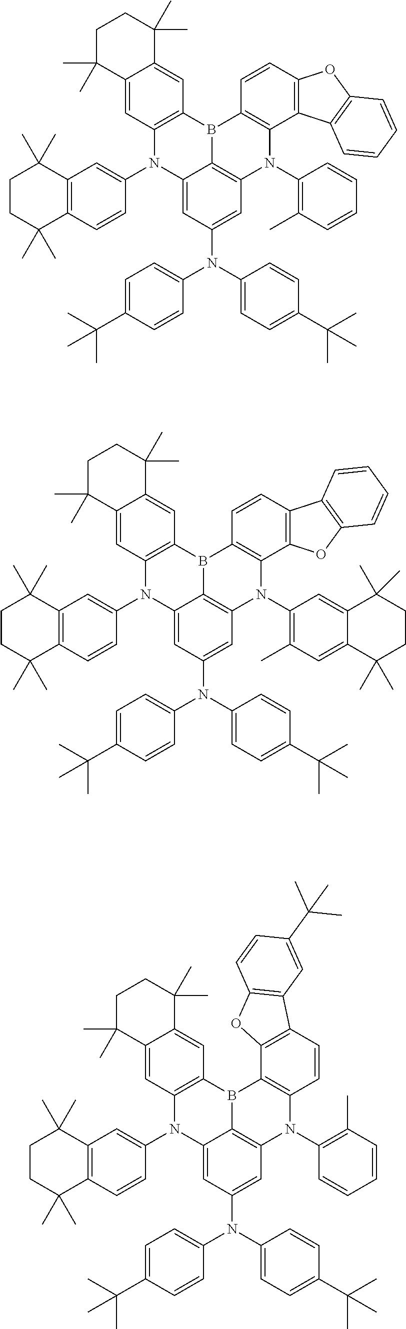 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3oc4ccccc4c3c21 ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(oc5ccccc54)c31)C(C)(C)CCC2(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2oc2ccc(C(C)(C)C)cc21]

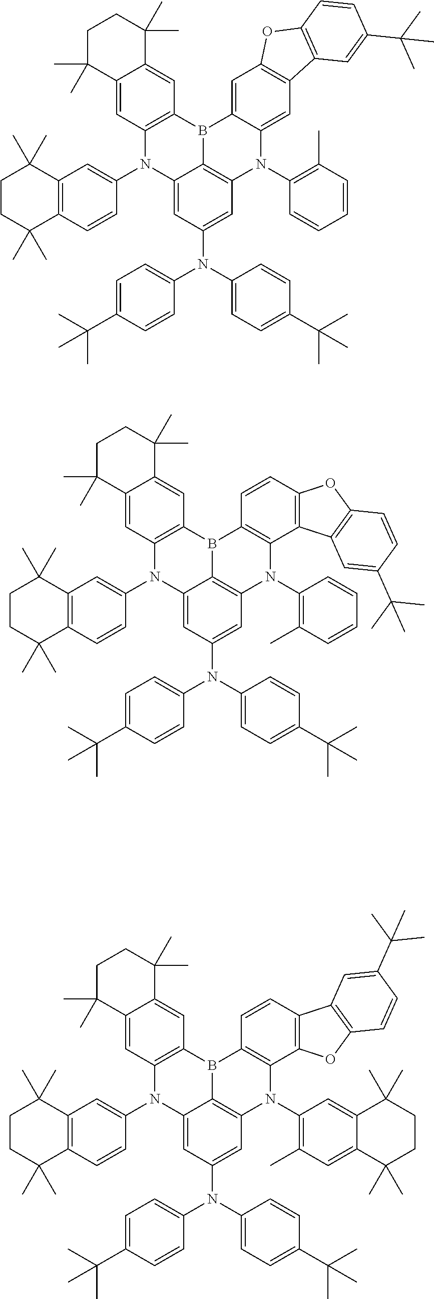 [SMILES: Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)oc1ccc(C(C)(C)C)cc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3oc4ccc(C(C)(C)C)cc4c3c21 ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(oc5ccc(C(C)(C)C)cc54)c31)C(C)(C)CCC2(C)C]

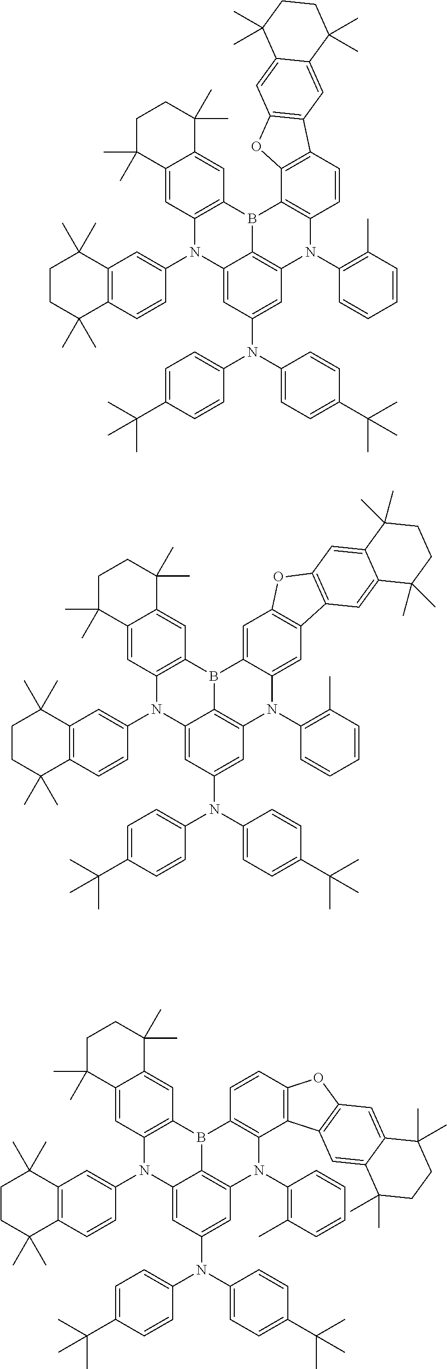

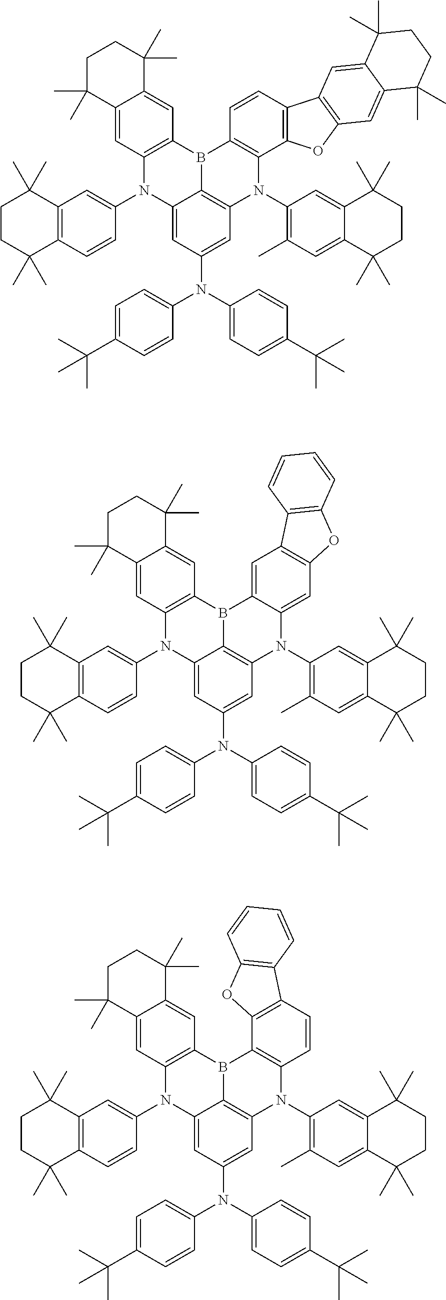 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(oc5cc6c(cc54)C(C)(C)CCC6(C)C)c31)C(C)(C)CCC2(C)C ; Cc1cc2c(cc1N1c3cc4oc5ccccc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3c1ccc1c3oc3ccccc31)C(C)(C)CCC2(C)C]

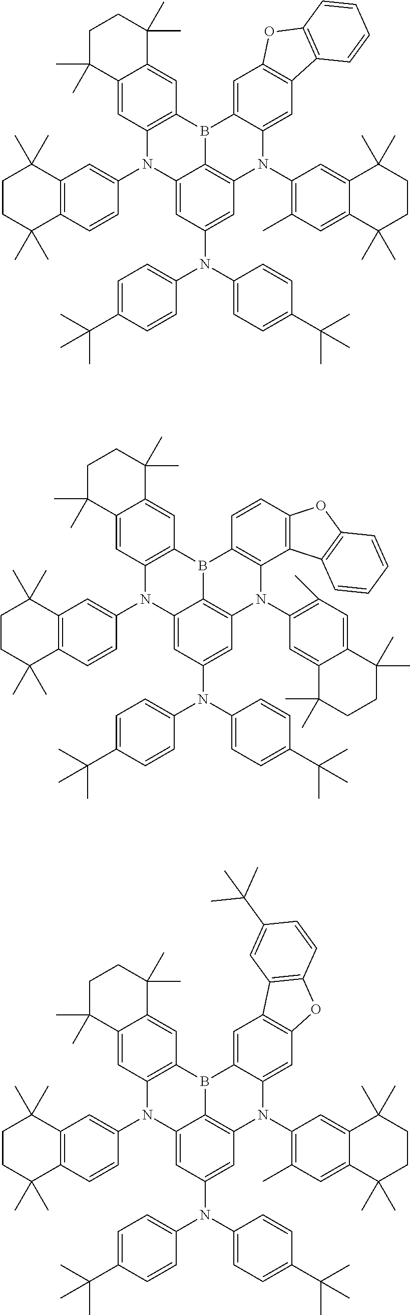 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)oc1ccccc14)C(C)(C)CCC2(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4oc5ccccc5c4c31)C(C)(C)CCC2(C)C ; Cc1cc2c(cc1N1c3cc4oc5ccc(C(C)(C)C)cc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C]

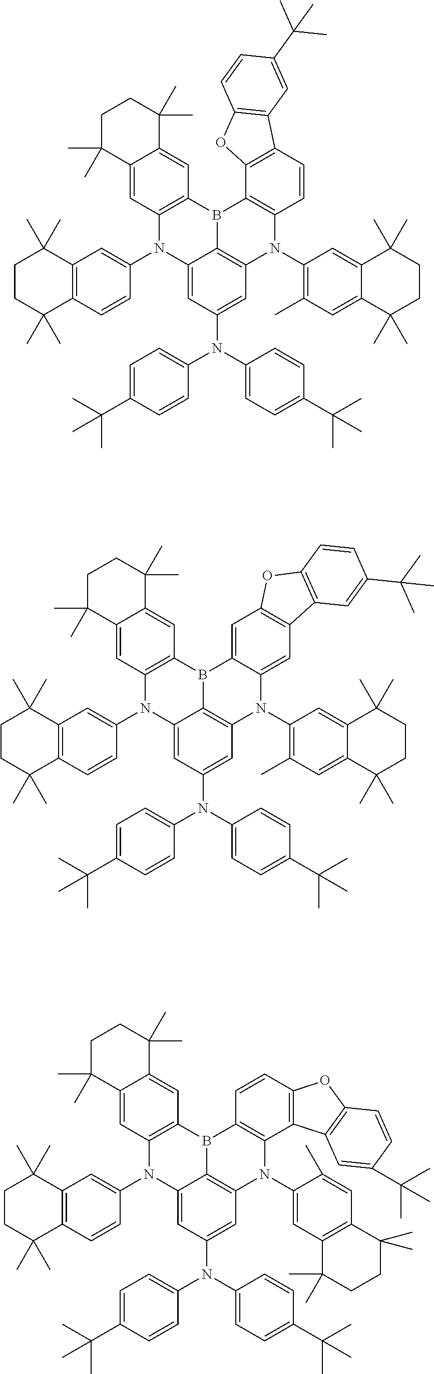

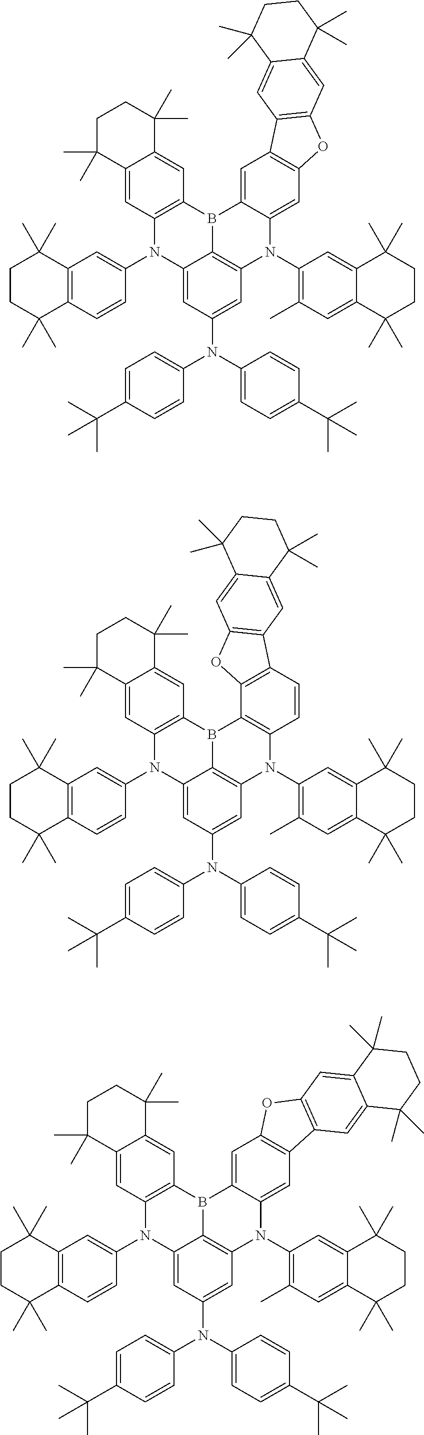

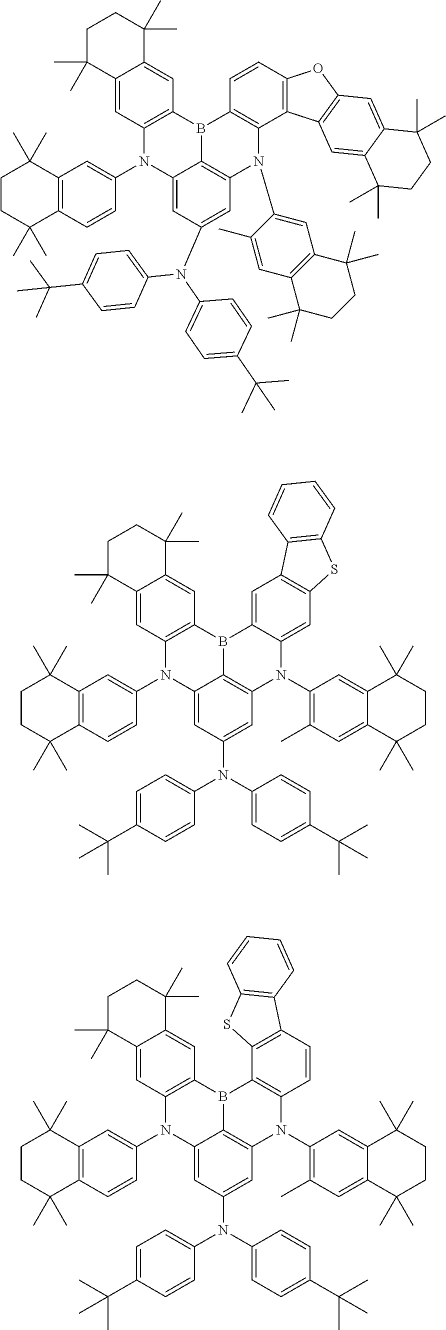 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4oc5cc6c(cc5c4c31)C(C)(C)CCC6(C)C)C(C)(C)CCC2(C)C ; Cc1cc2c(cc1N1c3cc4sc5ccccc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3c1ccc1c3sc3ccccc31)C(C)(C)CCC2(C)C]

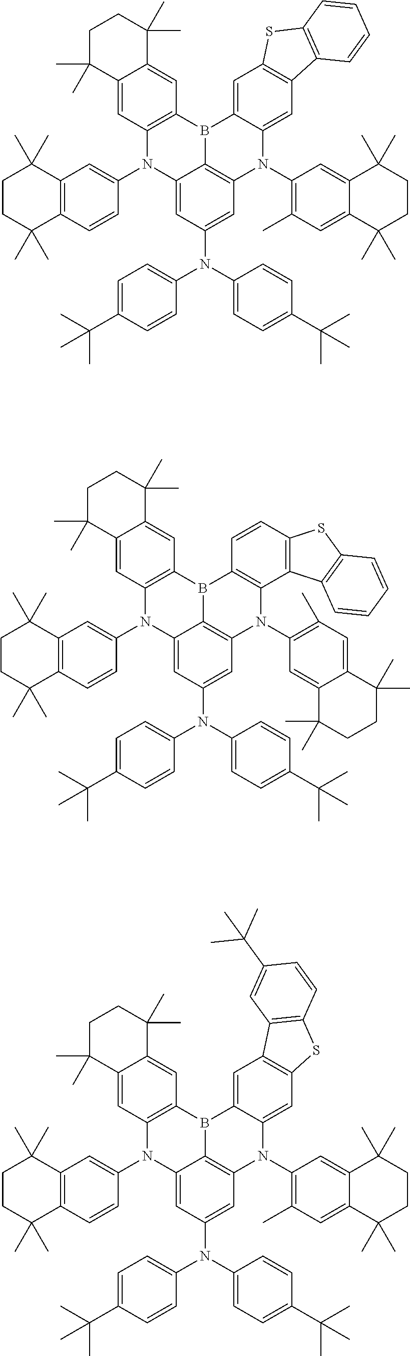 [SMILES: Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)sc1ccccc14)C(C)(C)CCC2(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4sc5ccccc5c4c31)C(C)(C)CCC2(C)C ; Cc1cc2c(cc1N1c3cc4sc5ccc(C(C)(C)C)cc5c4cc3B3c4cc5c(cc4N(c4ccc6c(c4)C(C)(C)CCC6(C)C)c4cc(N(c6ccc(C(C)(C)C)cc6)c6ccc(C(C)(C)C)cc6)cc1c43)C(C)(C)CCC5(C)C)C(C)(C)CCC2(C)C]

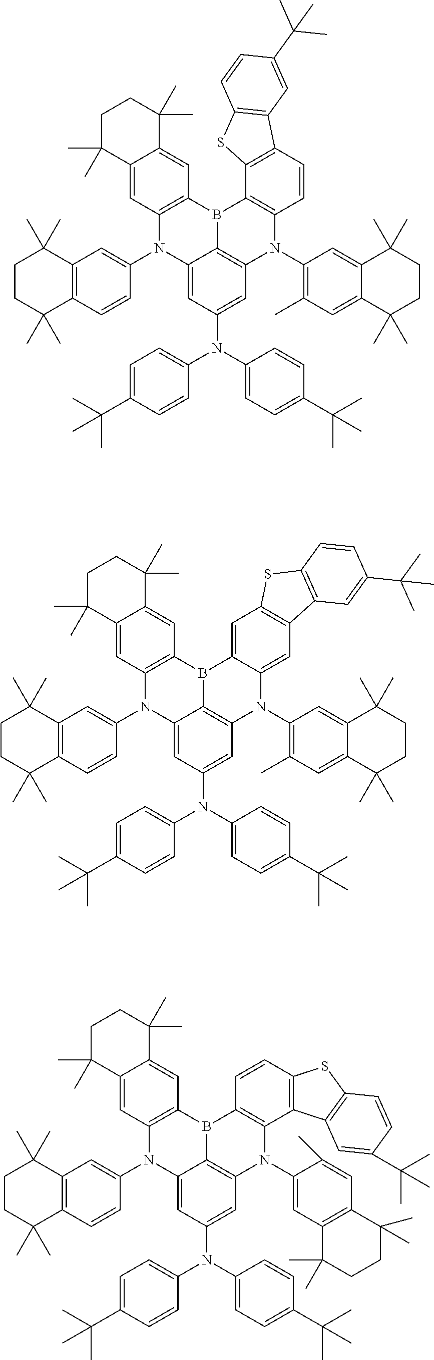

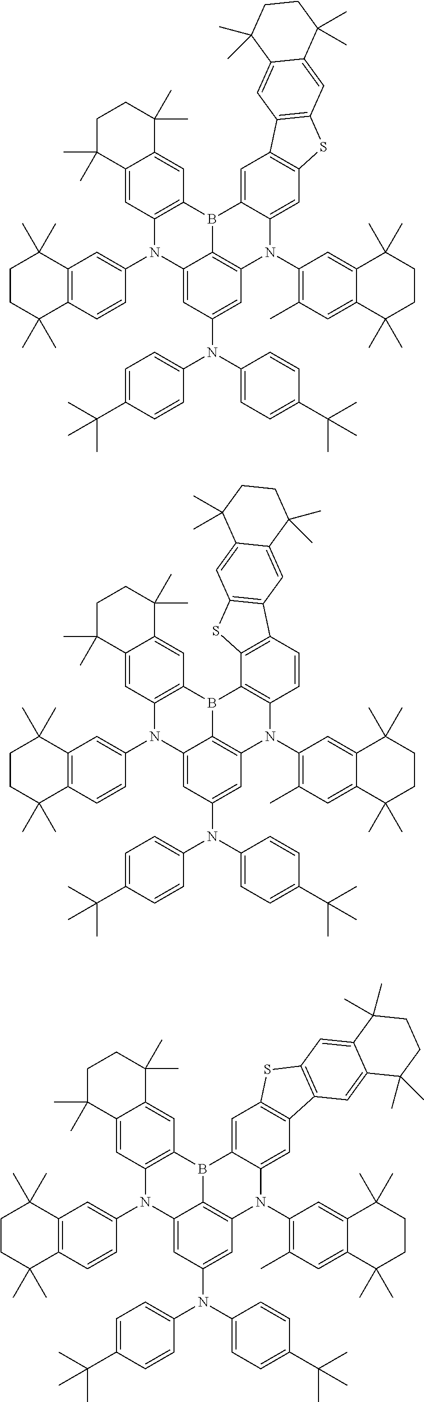

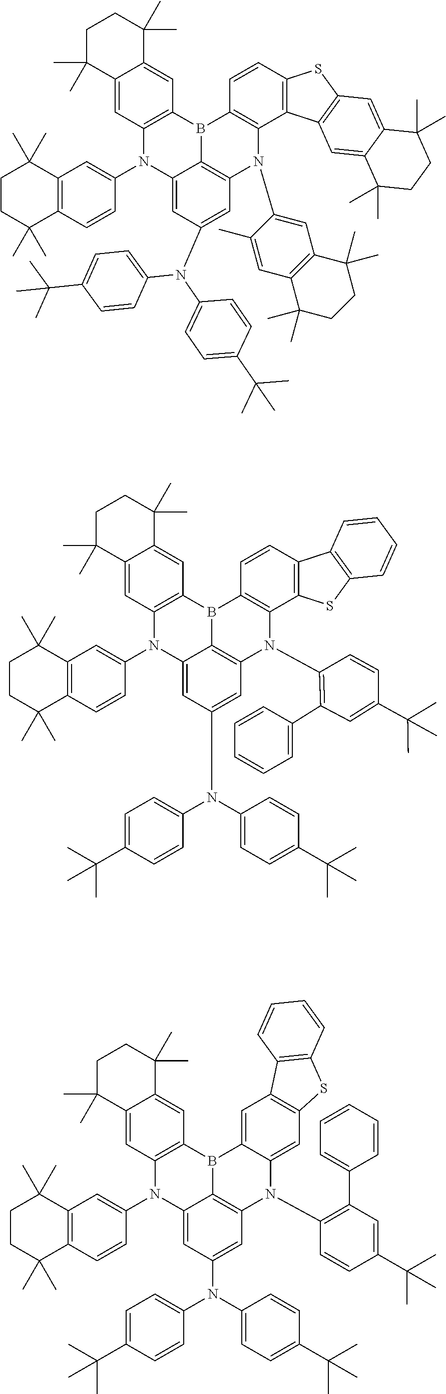 [SMILES: Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4sc5cc6c(cc5c4c31)C(C)(C)CCC6(C)C)C(C)(C)CCC2(C)C ; CC(C)(C)c1ccc(N(c2ccc(C(C)(C)C)cc2)c2cc3c4c(c2)N(c2ccc(C(C)(C)C)cc2-c2ccccc2)c2c(ccc5c2sc2ccccc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5sc6ccccc6c5cc2B4c2cc4c(cc2N3c2ccc3c(c2)C(C)(C)CCC3(C)C)C(C)(C)CCC4(C)C)cc1]

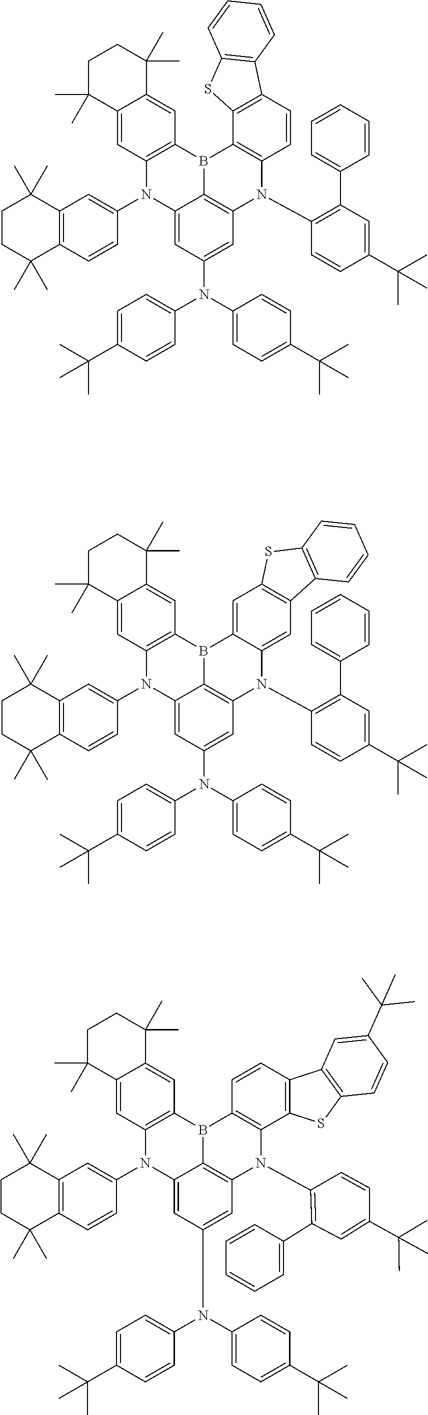 [SMILES: CC(C)(C)c1ccc(N(c2ccc(C(C)(C)C)cc2)c2cc3c4c(c2)N(c2ccc(C(C)(C)C)cc2-c2ccccc2)c2ccc5c(sc6ccccc65)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)C(C)(C)CCC3(C)C)C(C)(C)CCC4(C)C)sc2ccccc25)cc1 ; CC(C)(C)c1ccc(N(c2ccc(C(C)(C)C)cc2)c2cc3c4c(c2)N(c2ccc(C(C)(C)C)cc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)cc1]

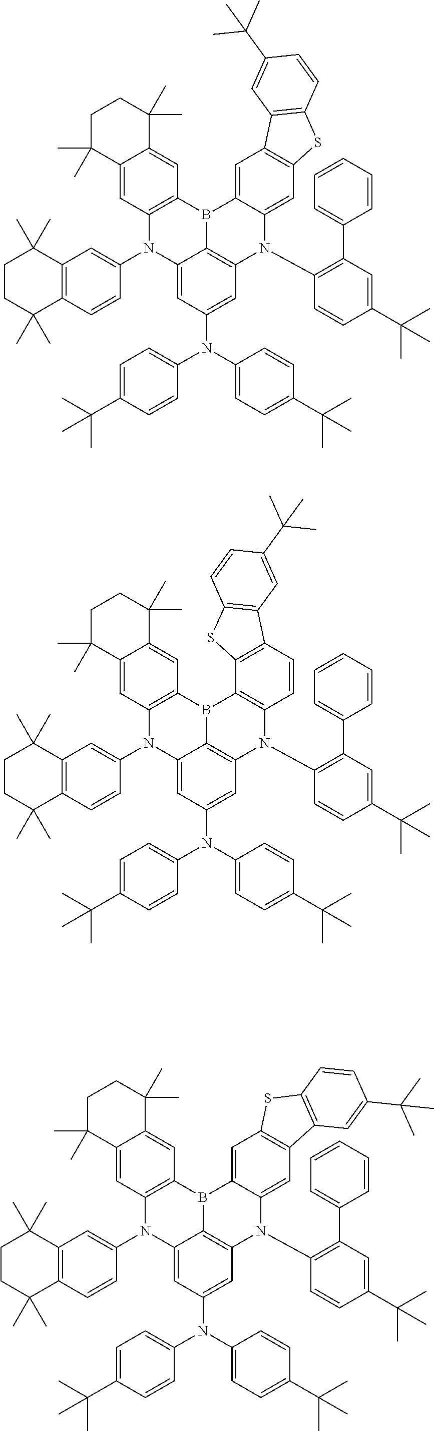

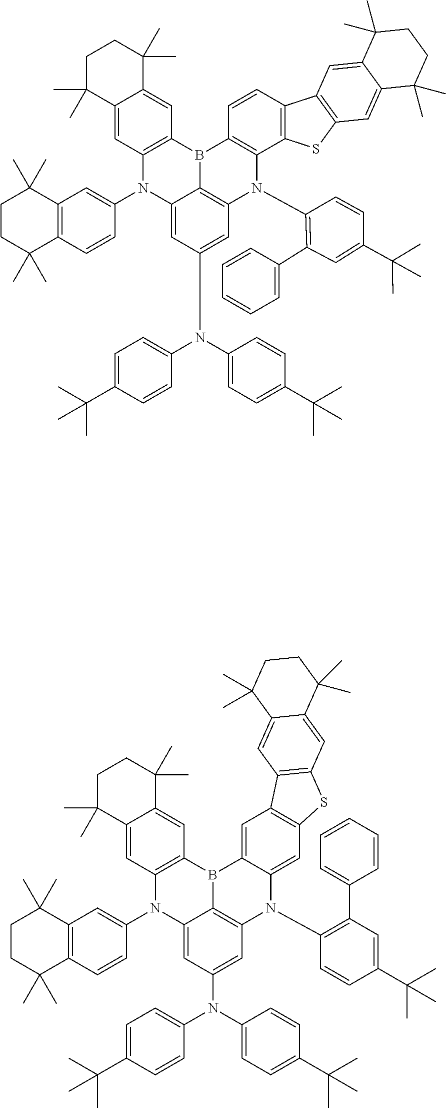 [SMILES: CC(C)(C)c1ccc(N(c2ccc(C(C)(C)C)cc2)c2cc3c4c(c2)N(c2ccc(C(C)(C)C)cc2-c2ccccc2)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)cc1]

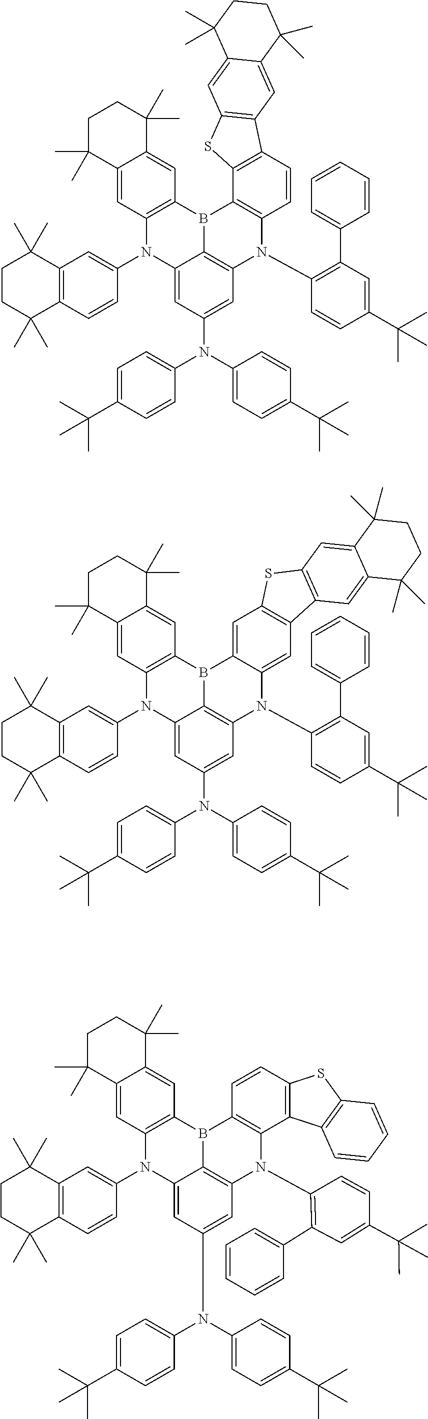

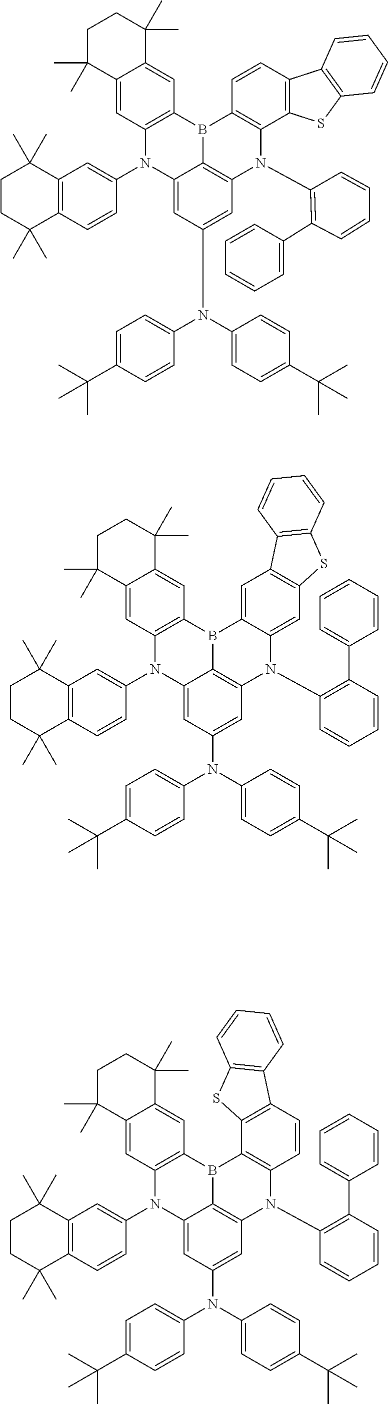 [SMILES: CC(C)(C)c1ccc(N(c2ccc(C(C)(C)C)cc2)c2cc3c4c(c2)N(c2ccccc2-c2ccccc2)c2c(ccc5c2sc2ccccc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5sc6ccccc6c5cc2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2ccc5c(sc6ccccc65)c2B4c2cc4c(cc2N3c2ccc3c(c2)C(C)(C)CCC3(C)C)C(C)(C)CCC4(C)C)cc1]

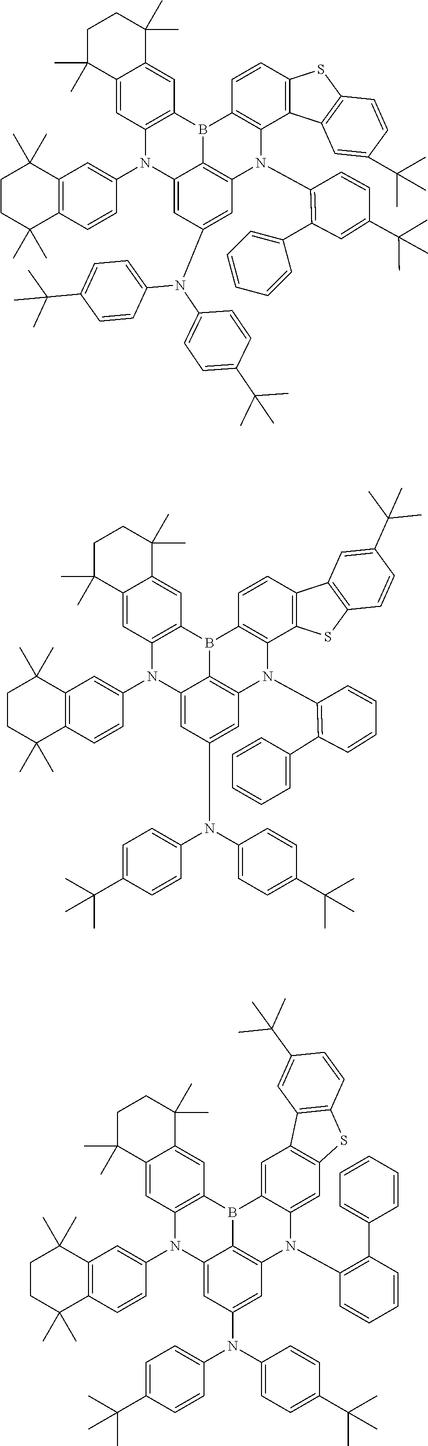 [SMILES: CC(C)(C)c1ccc(N(c2ccc(C(C)(C)C)cc2)c2cc3c4c(c2)N(c2ccc(C(C)(C)C)cc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2c(ccc5c2sc2ccc(C(C)(C)C)cc25)B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5sc6ccc(C(C)(C)C)cc6c5cc2B4c2cc4c(cc2N3c2ccc3c(c2)C(C)(C)CCC3(C)C)C(C)(C)CCC4(C)C)cc1]

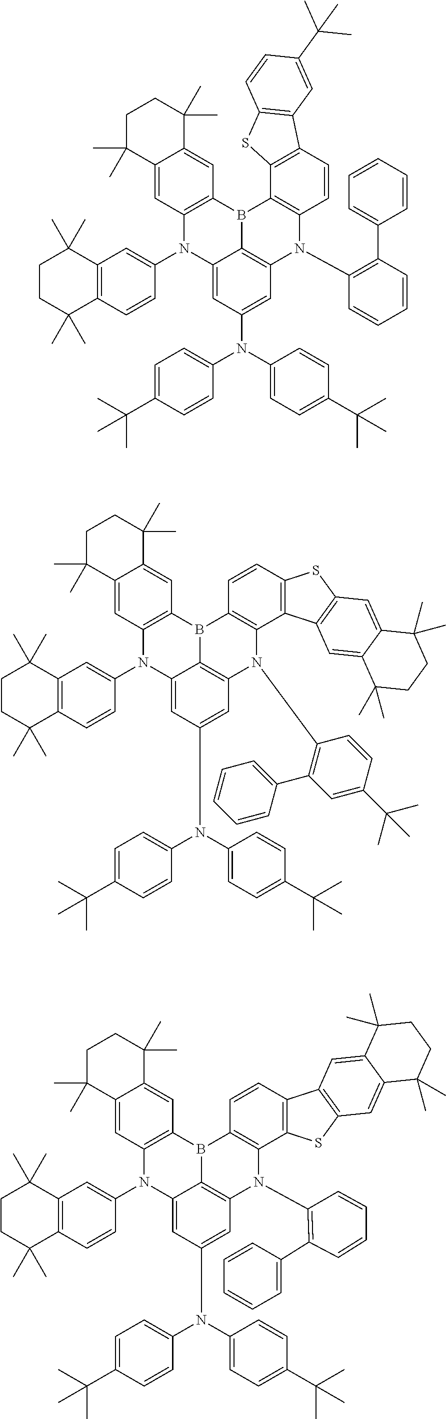

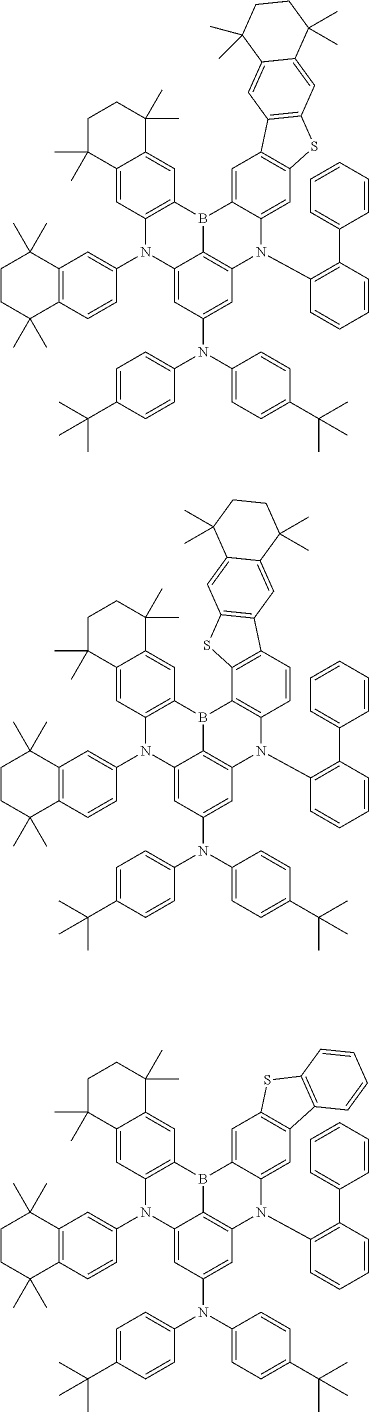 [SMILES: CC(C)(C)c1ccc(N(c2ccc(C(C)(C)C)cc2)c2cc3c4c(c2)N(c2ccccc2-c2ccccc2)c2cc5sc6cc7c(cc6c5cc2B4c2cc4c(cc2N3c2ccc3c(c2)C(C)(C)CCC3(C)C)C(C)(C)CCC4(C)C)C(C)(C)CCC7(C)C)cc1 ; CC(C)(C)c1ccc(N(c2ccc(C(C)(C)C)cc2)c2cc3c4c(c2)N(c2ccccc2-c2ccccc2)c2ccc5c(sc6cc7c(cc65)C(C)(C)CCC7(C)C)c2B4c2cc4c(cc2N3c2ccc3c(c2)C(C)(C)CCC3(C)C)C(C)(C)CCC4(C)C)cc1 ; CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccccc25)cc1]

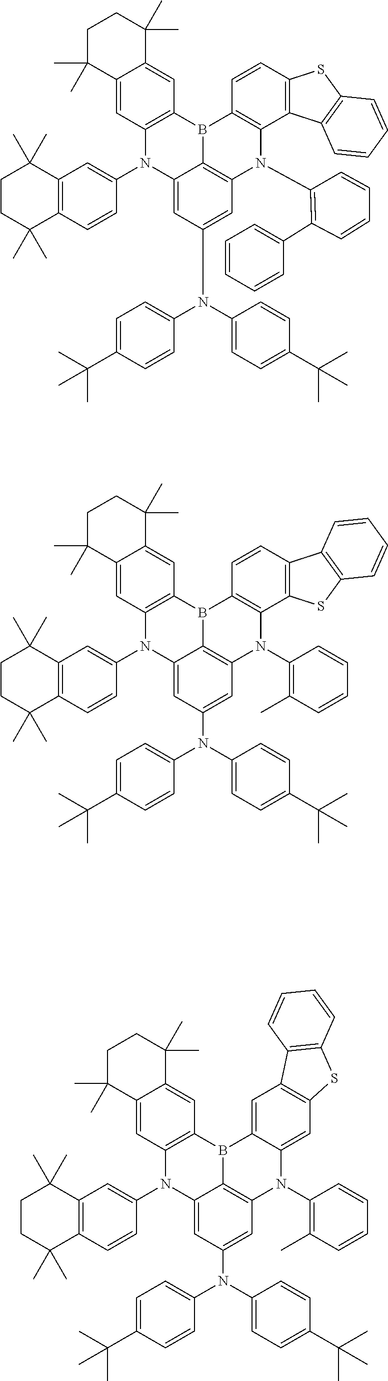 [SMILES: CC(C)(C)c1ccc(N(c2ccc(C(C)(C)C)cc2)c2cc3c4c(c2)N(c2ccccc2-c2ccccc2)c2c(ccc5sc6ccccc6c25)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(sc4ccccc43)c21 ; Cc1ccccc1N1c2cc3sc4ccccc4c3cc2B2c3cc4c(cc3N(c3ccc5c(c3)C(C)(C)CCC5(C)C)c3cc(N(c5ccc(C(C)(C)C)cc5)c5ccc(C(C)(C)C)cc5)cc1c32)C(C)(C)CCC4(C)C]

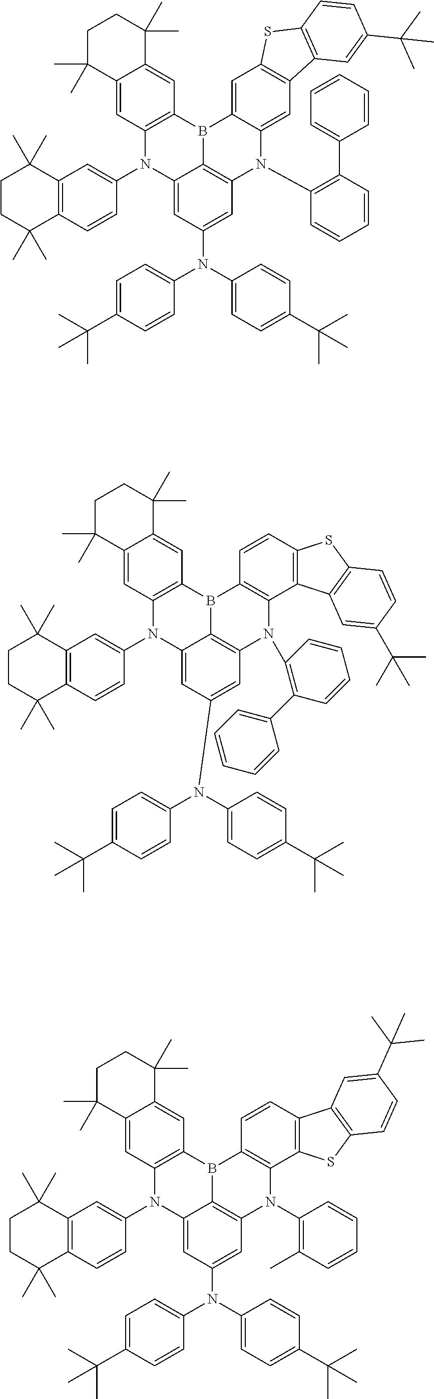 [SMILES: CC(C)(C)c1ccc(N(c2ccc(C(C)(C)C)cc2)c2cc3c4c(c2)N(c2ccccc2-c2ccccc2)c2cc5c(cc2B4c2cc4c(cc2N3c2ccc3c(c2)C(C)(C)CCC3(C)C)C(C)(C)CCC4(C)C)sc2ccc(C(C)(C)C)cc25)cc1 ; CC(C)(C)c1ccc(N(c2ccc(C(C)(C)C)cc2)c2cc3c4c(c2)N(c2ccccc2-c2ccccc2)c2c(ccc5sc6ccc(C(C)(C)C)cc6c25)B4c2cc4c(cc2N3c2ccc3c(c2)C(C)(C)CCC3(C)C)C(C)(C)CCC4(C)C)cc1 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(sc4ccc(C(C)(C)C)cc43)c21]

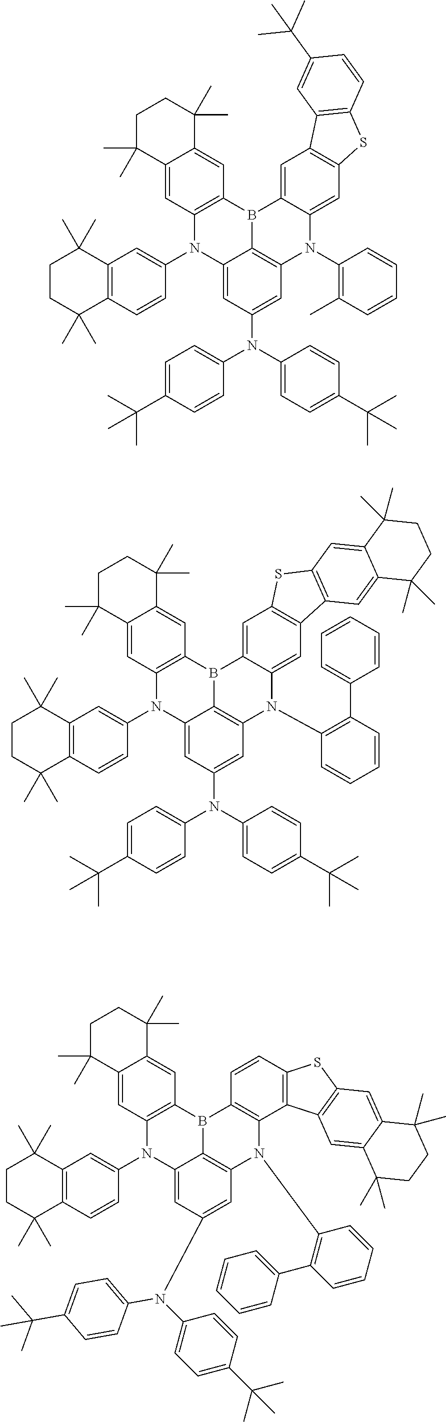

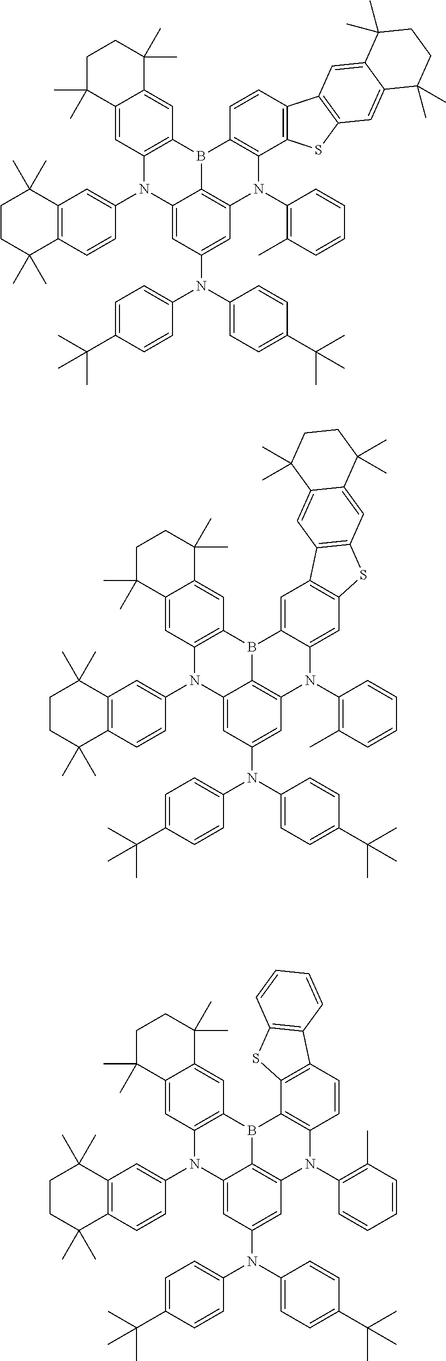 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3c(sc4cc5c(cc43)C(C)(C)CCC5(C)C)c21 ; Cc1ccccc1N1c2cc3sc4cc5c(cc4c3cc2B2c3cc4c(cc3N(c3ccc6c(c3)C(C)(C)CCC6(C)C)c3cc(N(c6ccc(C(C)(C)C)cc6)c6ccc(C(C)(C)C)cc6)cc1c32)C(C)(C)CCC4(C)C)C(C)(C)CCC5(C)C ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2sc2ccccc21]

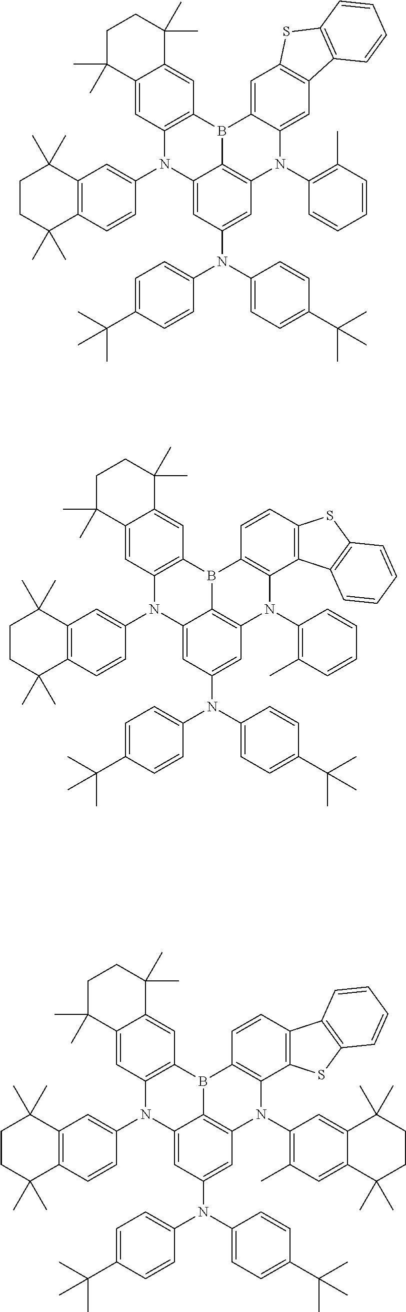 [SMILES: Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)sc1ccccc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3sc4ccccc4c3c21 ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(sc5ccccc54)c31)C(C)(C)CCC2(C)C]

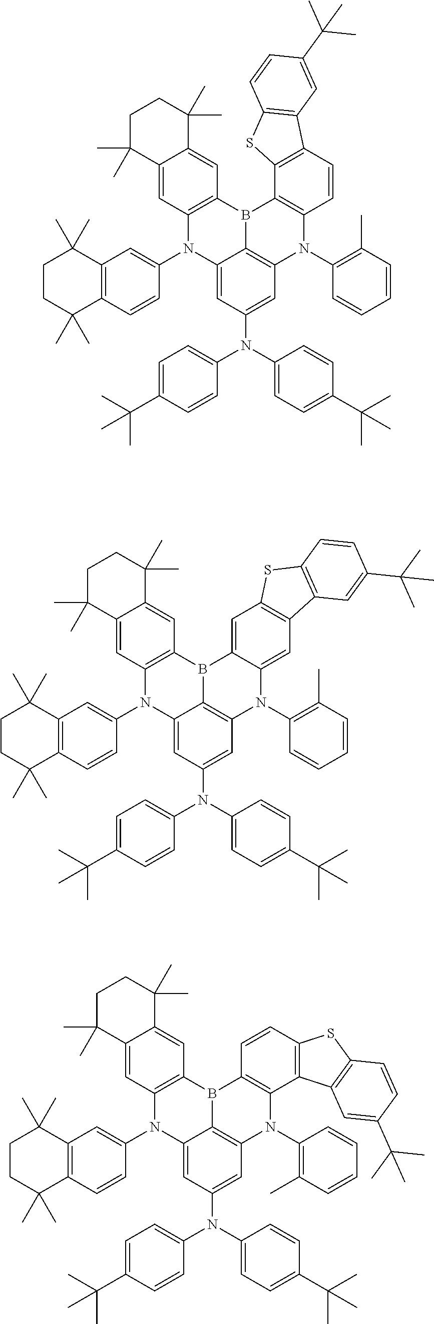 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2c1ccc1c2sc2ccc(C(C)(C)C)cc21 ; Cc1ccccc1N1c2cc3c(cc2B2c4cc5c(cc4N(c4ccc6c(c4)C(C)(C)CCC6(C)C)c4cc(N(c6ccc(C(C)(C)C)cc6)c6ccc(C(C)(C)C)cc6)cc1c42)C(C)(C)CCC5(C)C)sc1ccc(C(C)(C)C)cc13 ; Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3sc4ccc(C(C)(C)C)cc4c3c21]

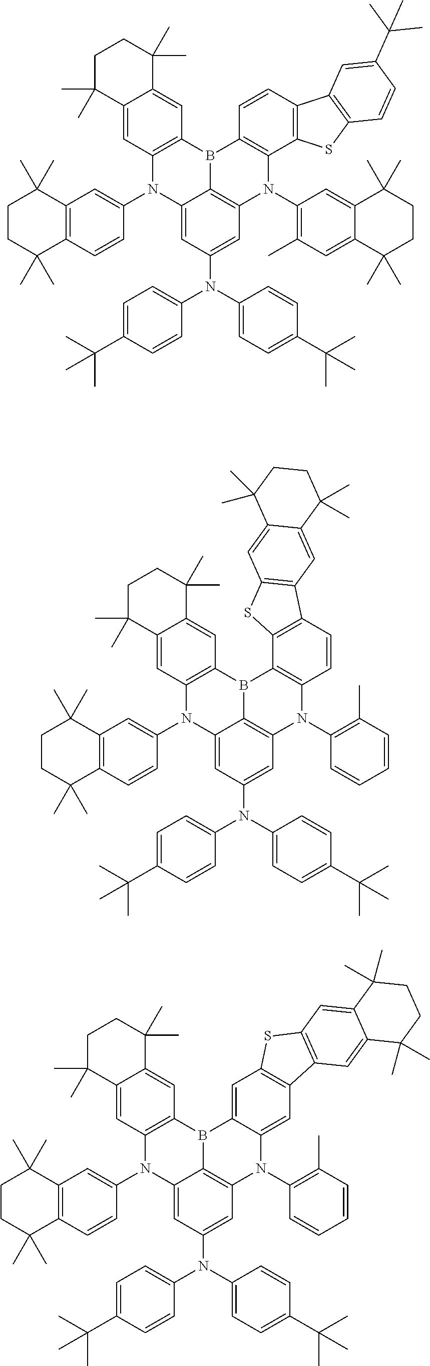

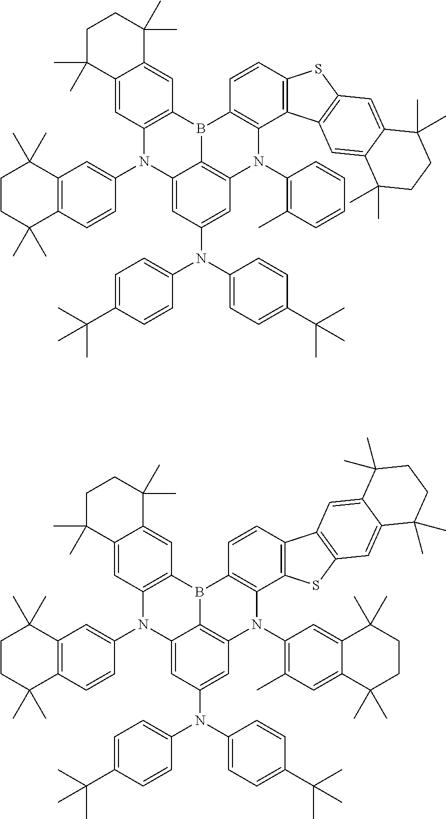 [SMILES: Cc1ccccc1N1c2cc(N(c3ccc(C(C)(C)C)cc3)c3ccc(C(C)(C)C)cc3)cc3c2B(c2cc4c(cc2N3c2ccc3c(c2)C(C)(C)CCC3(C)C)C(C)(C)CCC4(C)C)c2ccc3sc4cc5c(cc4c3c21)C(C)(C)CCC5(C)C ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(sc5cc6c(cc54)C(C)(C)CCC6(C)C)c31)C(C)(C)CCC2(C)C]

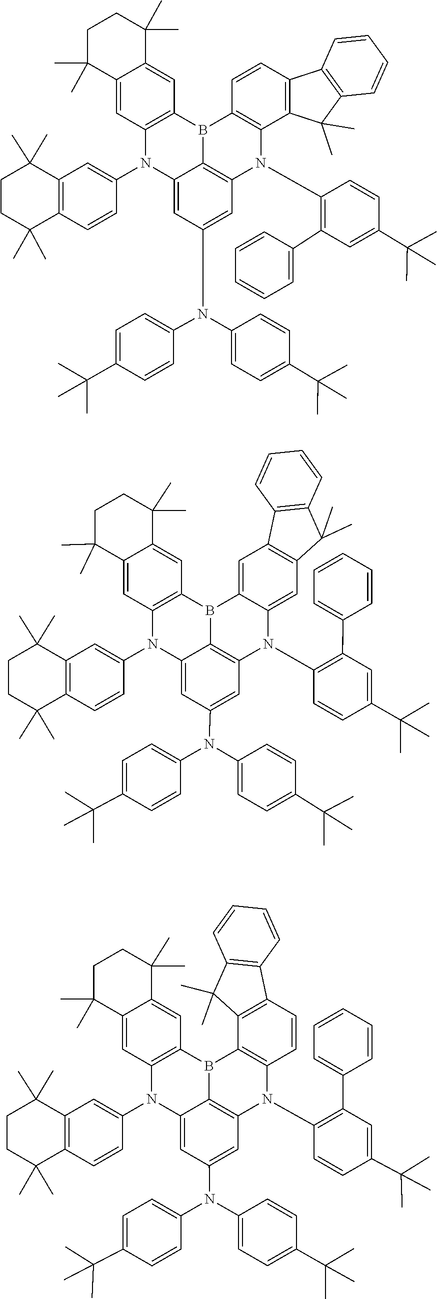

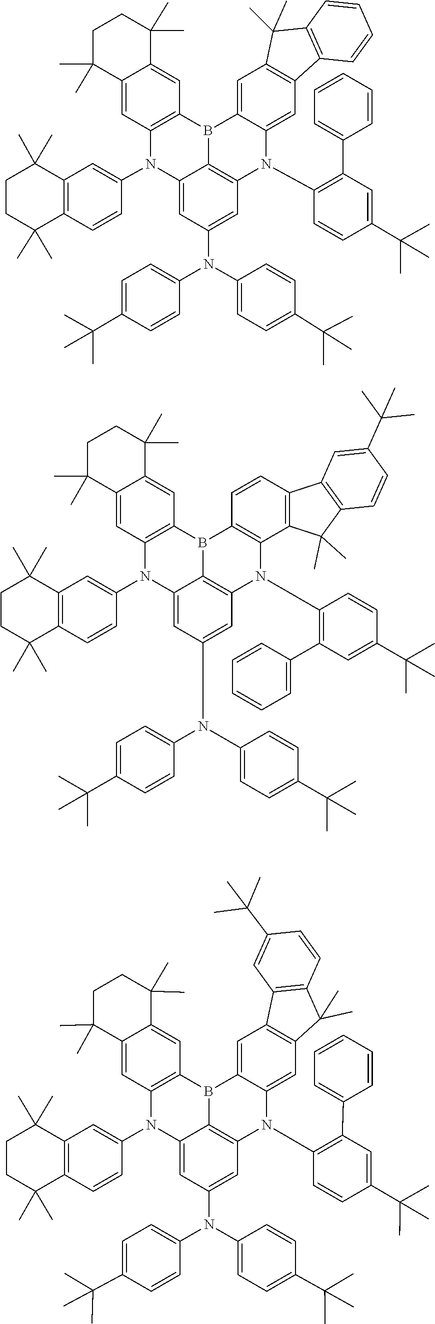

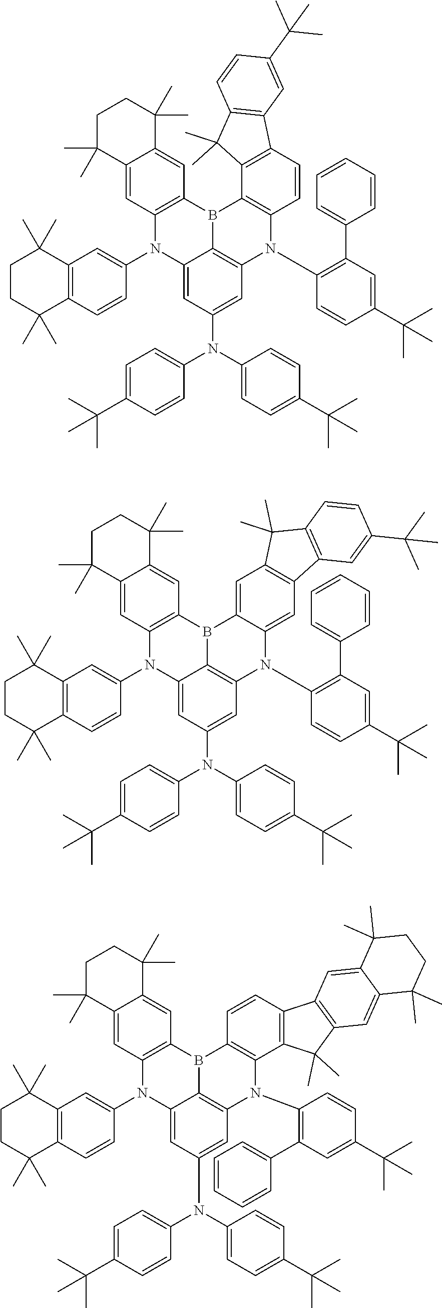

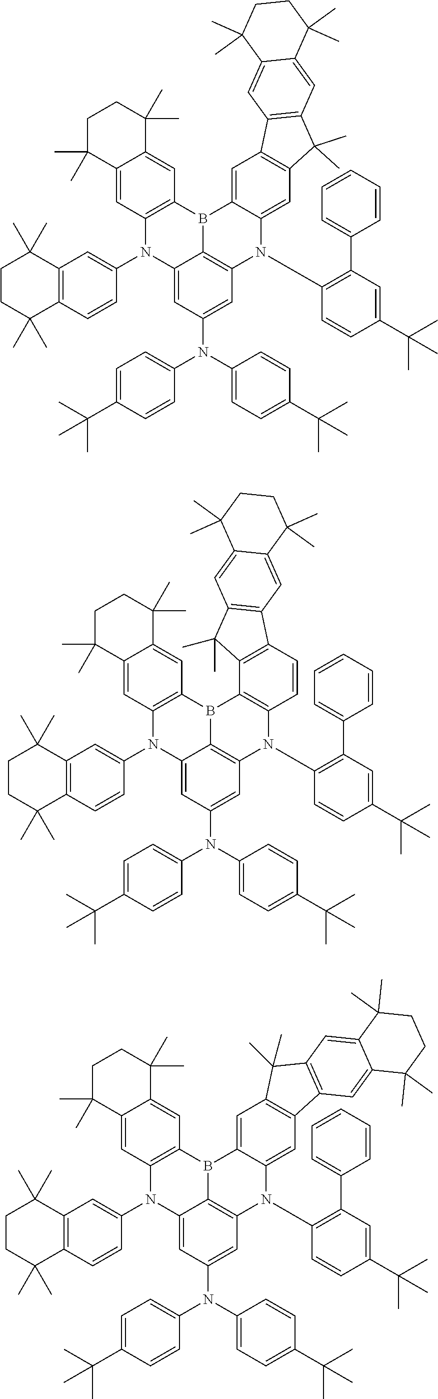

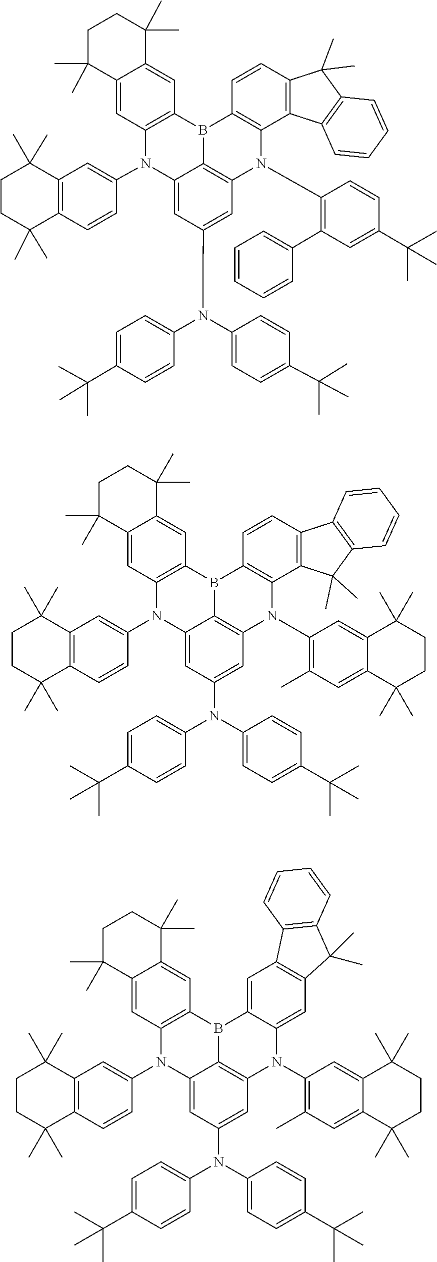 [SMILES: CC(C)(C)c1ccc(N(c2ccc(C(C)(C)C)cc2)c2cc3c4c(c2)N(c2ccc(C(C)(C)C)cc2-c2ccccc2)c2c(ccc5c2-c2ccccc2C5(C)C)B4c2cc4c(cc2N3c2ccc3c(c2)C(C)(C)CCC3(C)C)C(C)(C)CCC4(C)C)cc1 ; Cc1cc2c(cc1N1c3cc(N(c4ccc(C(C)(C)C)cc4)c4ccc(C(C)(C)C)cc4)cc4c3B(c3cc5c(cc3N4c3ccc4c(c3)C(C)(C)CCC4(C)C)C(C)(C)CCC5(C)C)c3ccc4c(c31)C(C)(C)c1ccccc1-4)C(C)(C)CCC2(C)C ; Cc1cc2c(cc1N1c3cc4c(cc3B3c5cc6c(cc5N(c5ccc7c(c5)C(C)(C)CCC7(C)C)c5cc(N(c7ccc(C(C)(C)C)cc7)c7ccc(C(C)(C)C)cc7)cc1c53)C(C)(C)CCC6(C)C)-c1ccccc1C4(C)C)C(C)(C)CCC2(C)C]

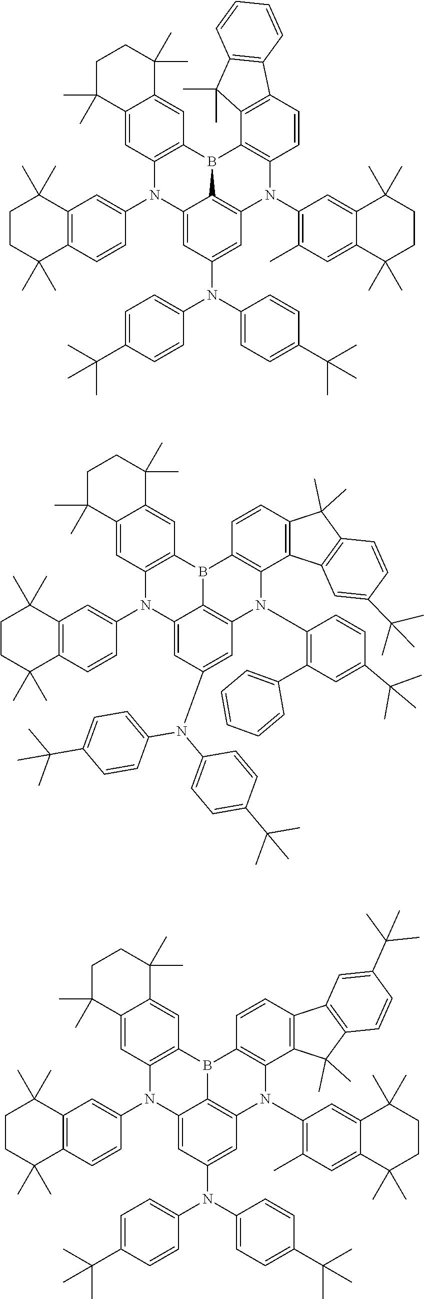

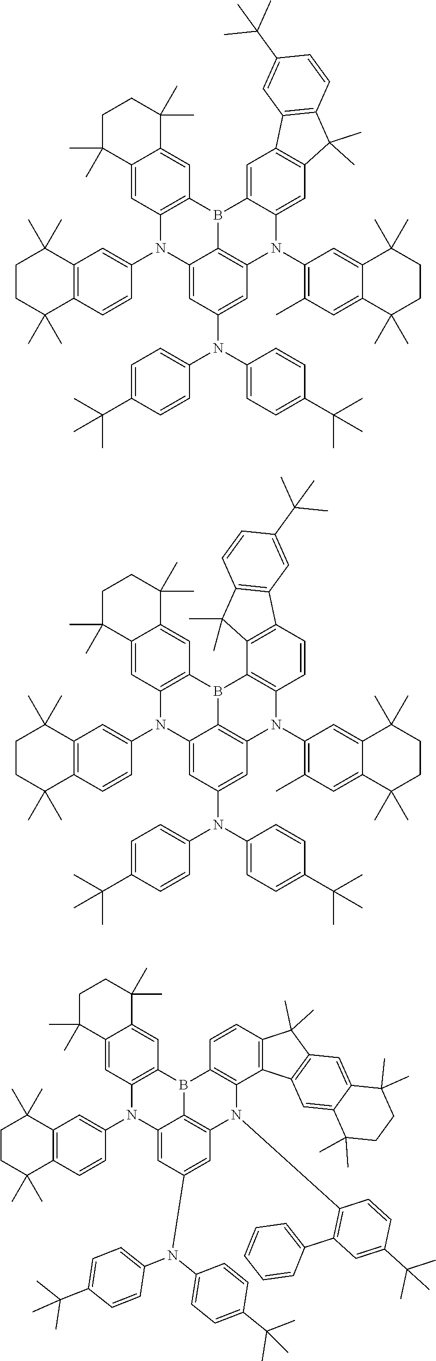

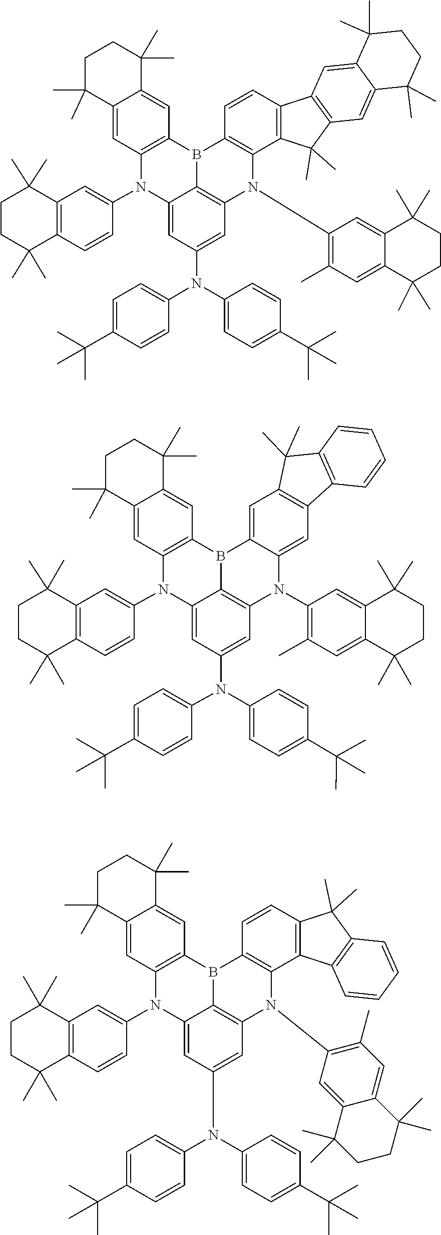

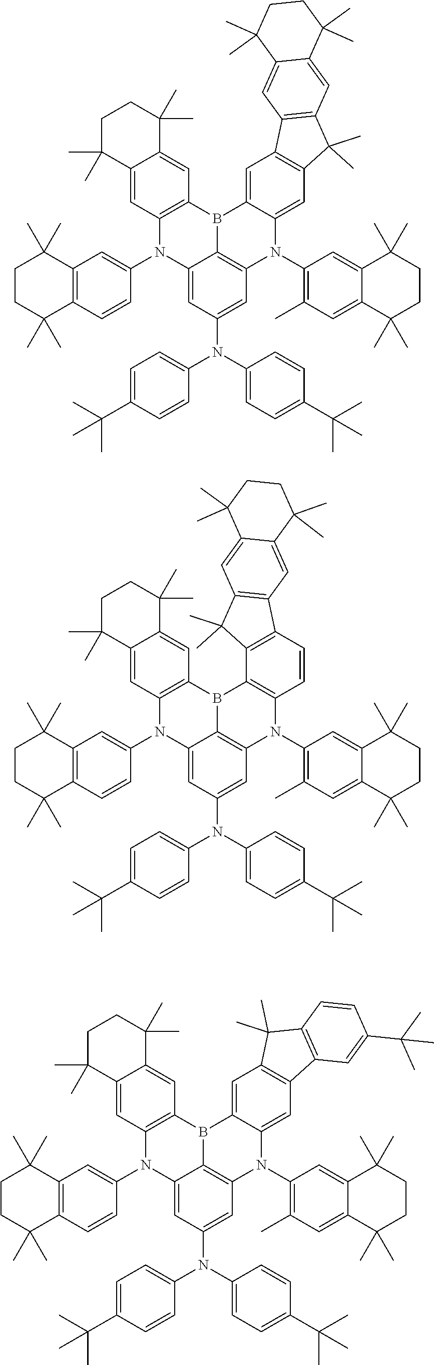

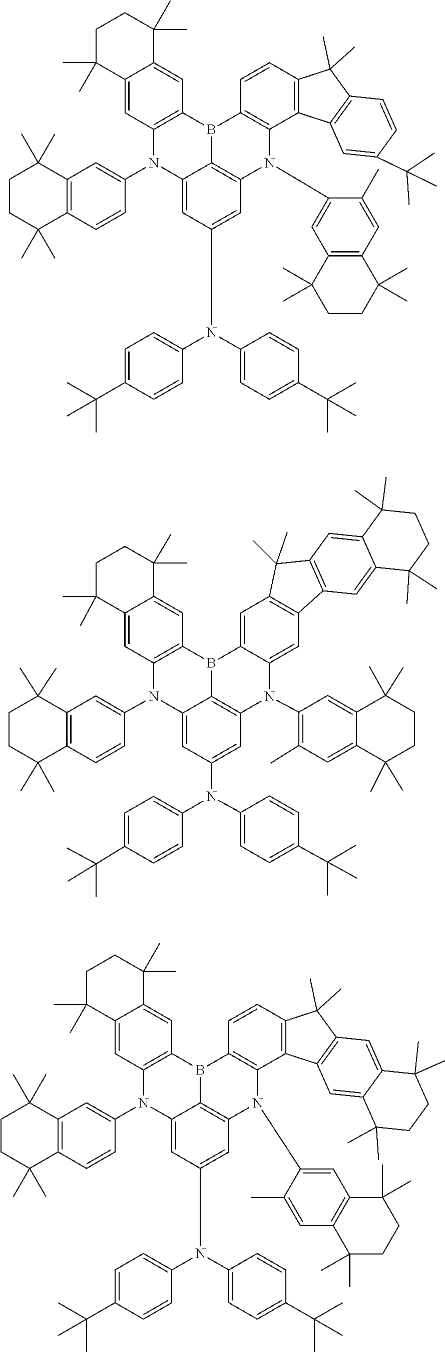

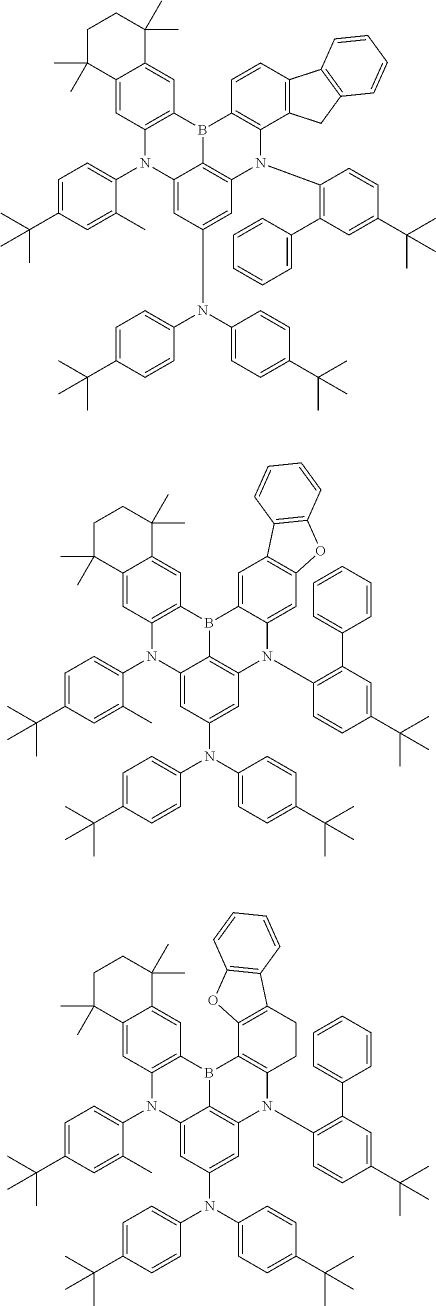

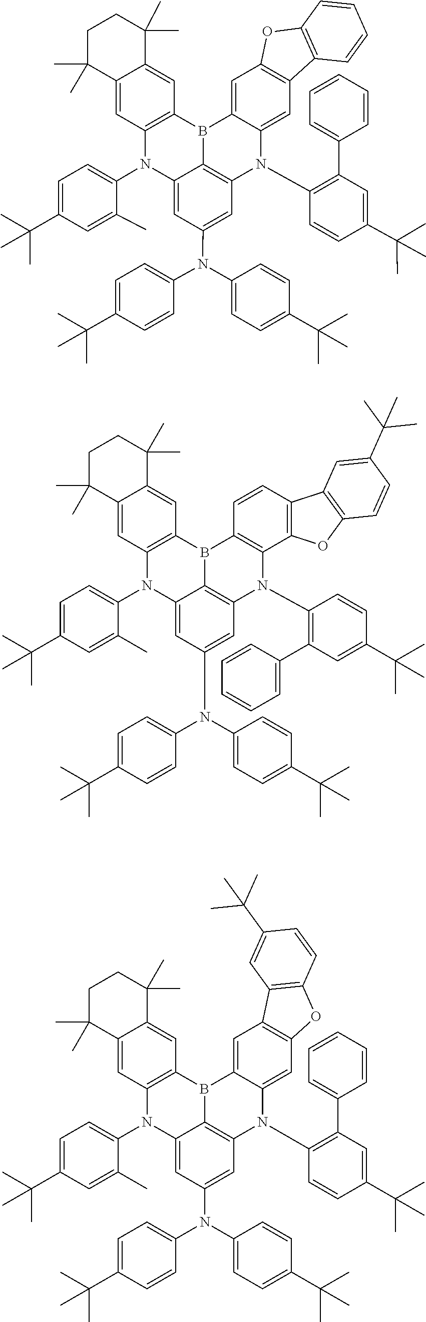

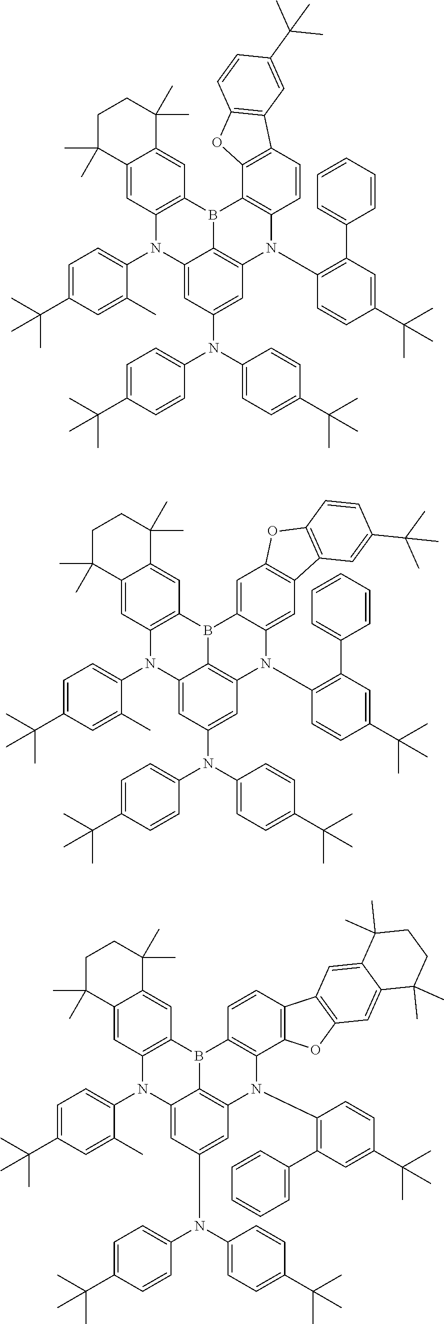

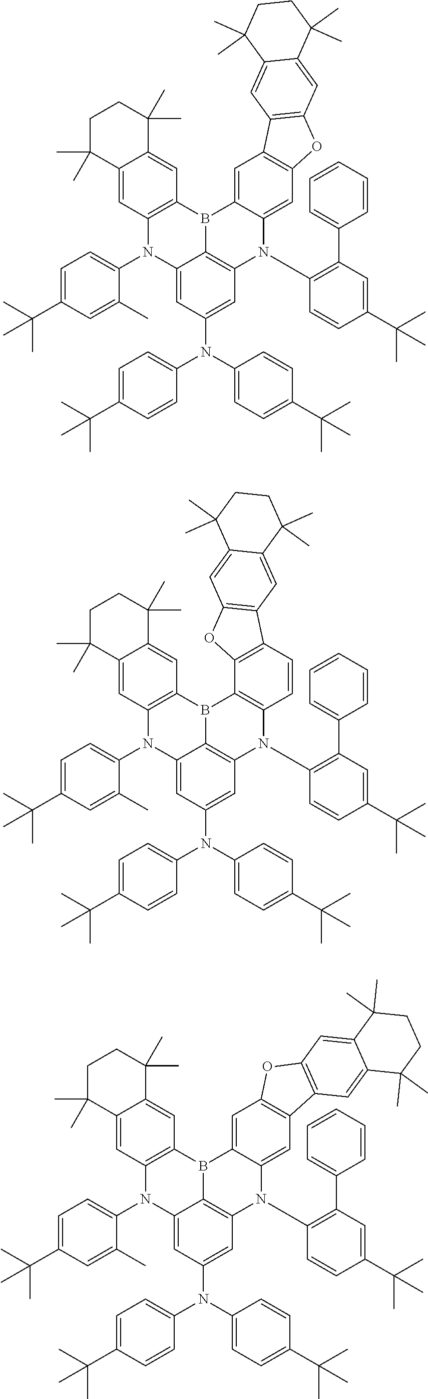

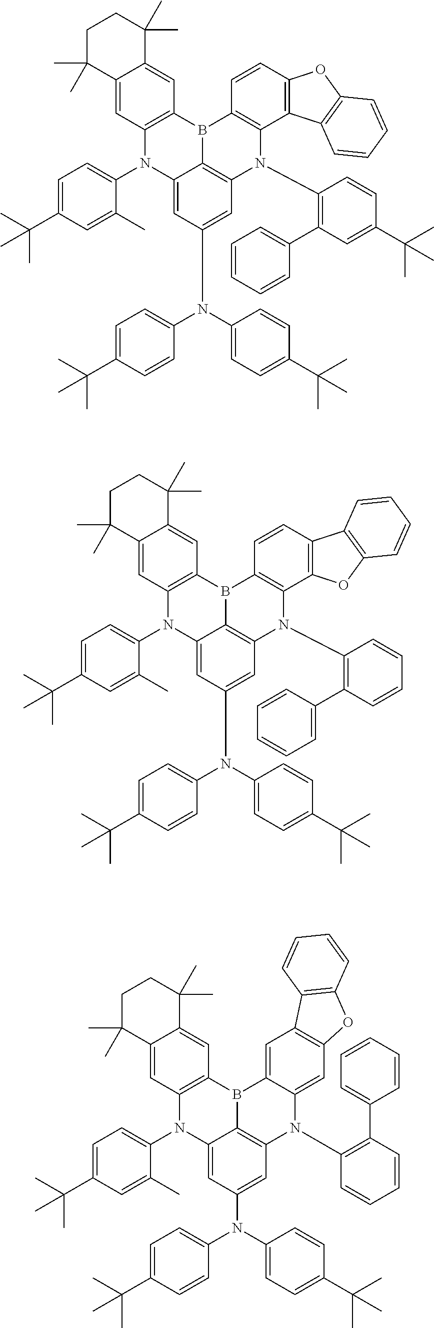

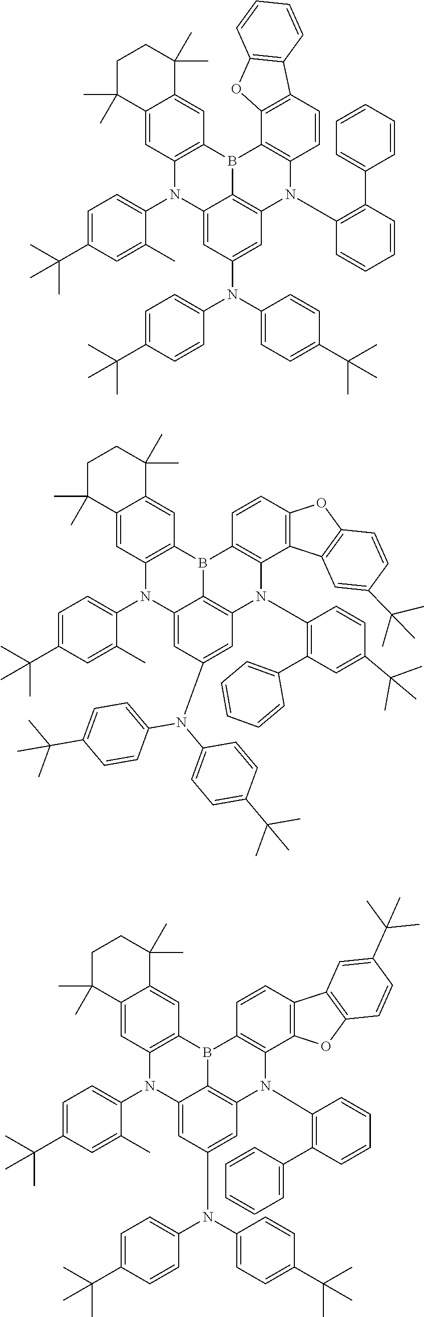

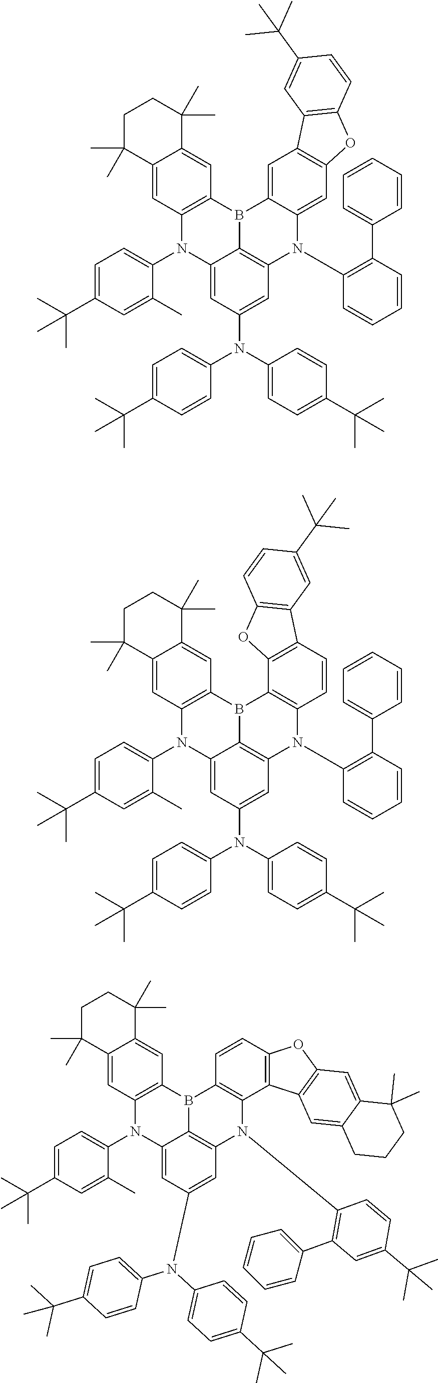 [SMILES: Cc1cc(C(C)(C)C)ccc1N1c2cc3c(cc2B2c4cc5c(cc4N(c4ccccc4-c4ccccc4)c4cc(N(c6ccc(C(C)(C)C)cc6)c6ccc(C(C)(C)C)cc6)cc1c42)oc1ccc(C(C)(C)C)cc15)C(C)(C)CCC3(C)C ; Cc1cc(C(C)(C)C)ccc1N1c2cc3c(cc2B2c4c1cc(N(c1ccc(C(C)(C)C)cc1)c1ccc(C(C)(C)C)cc1)cc4N(c1ccccc1-c1ccccc1)c1ccc4c(oc5ccc(C(C)(C)C)cc54)c12)C(C)(C)CCC3(C)C ; Cc1cc(C(C)(C)C)ccc1N1c2cc3c(cc2B2c4ccc5oc6cc7c(cc6c5c4N(c4ccc(C(C)(C)C)cc4-c4ccccc4)c4cc(N(c5ccc(C(C)(C)C)cc5)c5ccc(C(C)(C)C)cc5)cc1c42)CCCC7(C)C)C(C)(C)CCC3(C)C]

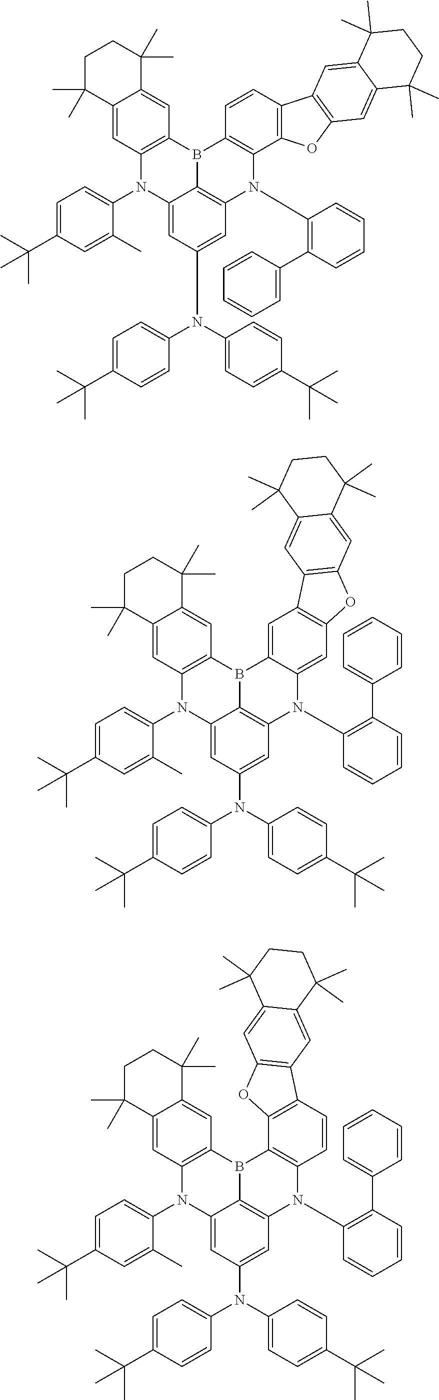

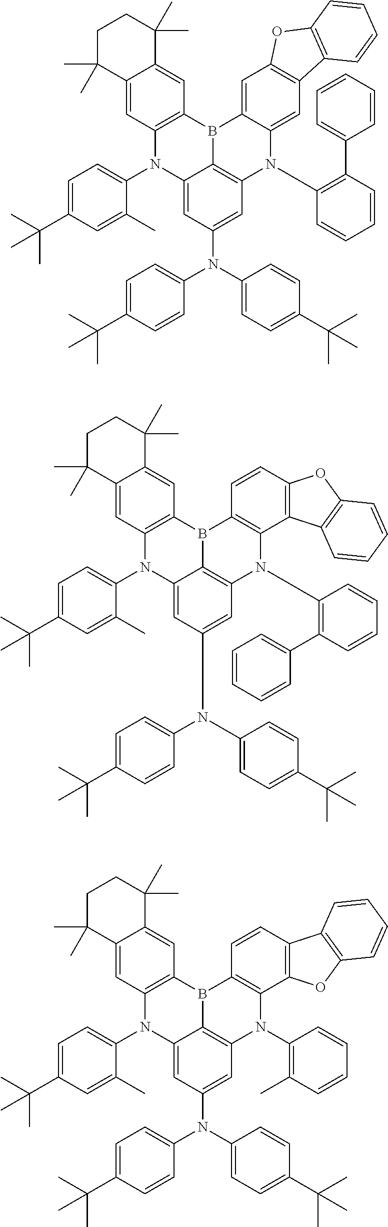 [SMILES: Cc1cc(C(C)(C)C)ccc1N1c2cc3c(cc2B2c4cc5oc6ccccc6c5cc4N(c4ccccc4-c4ccccc4)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4ccc5oc6ccccc6c5c4N(c4ccccc4-c4ccccc4)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4ccc5c(oc6ccccc65)c4N(c4ccccc4C)c4cc(N(c5ccc(C(C)(C)C)cc5)c5ccc(C(C)(C)C)cc5)cc1c42)C(C)(C)CCC3(C)C]

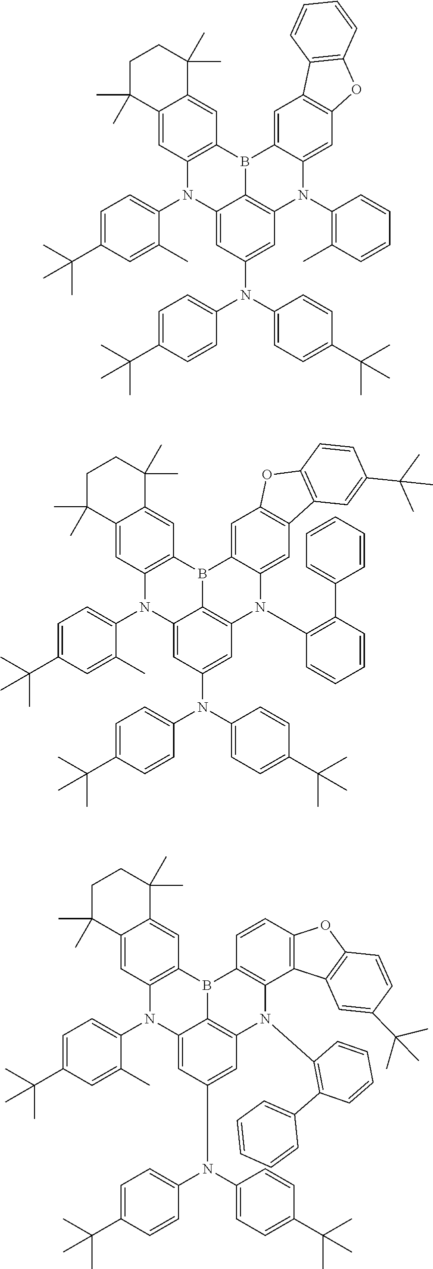

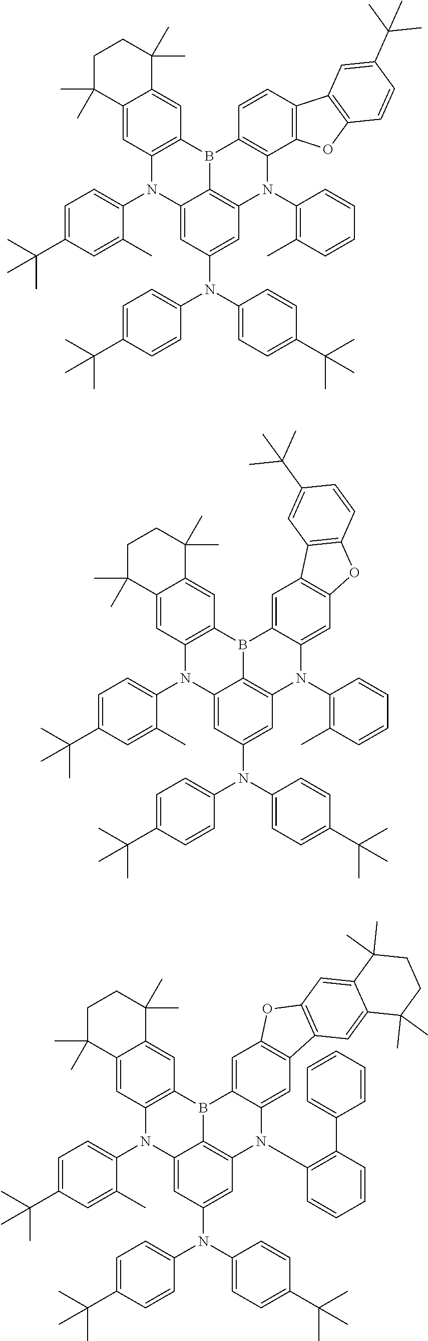

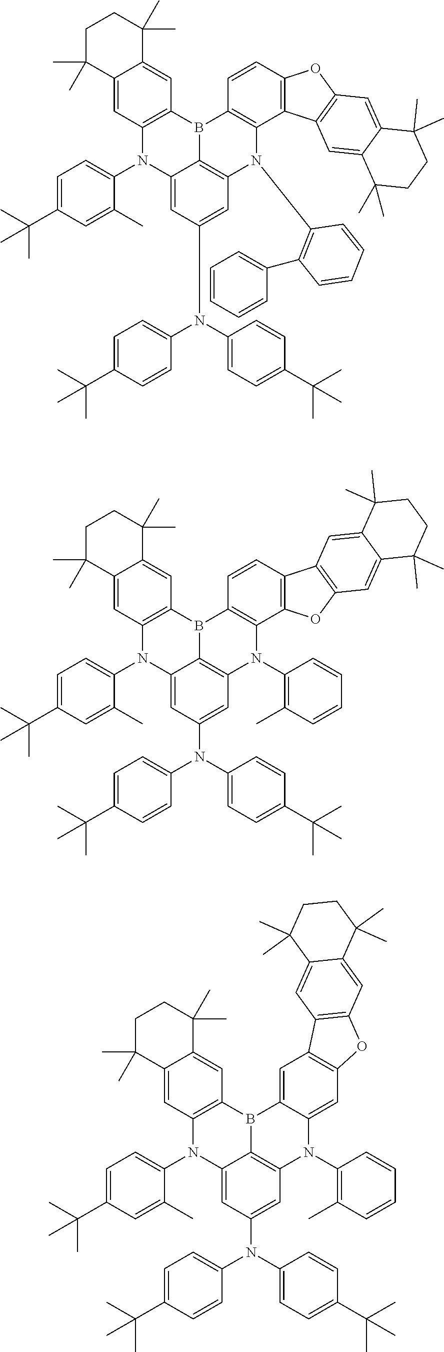

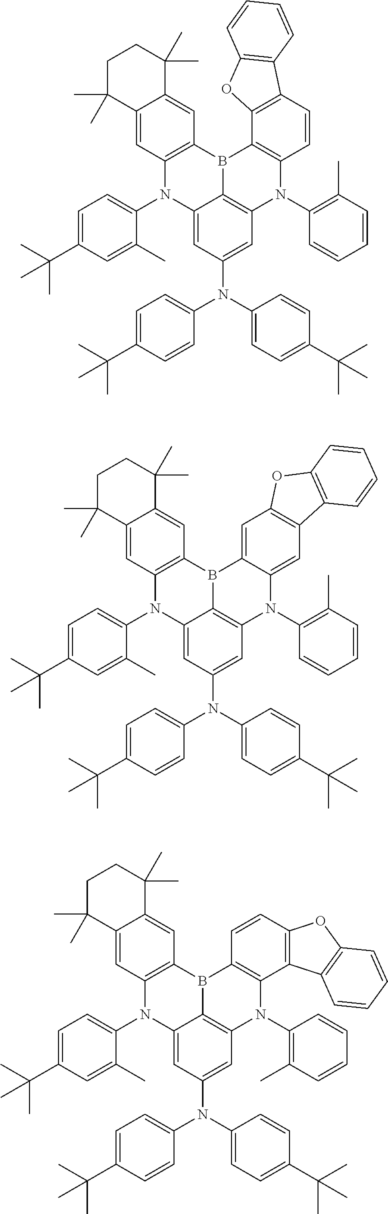

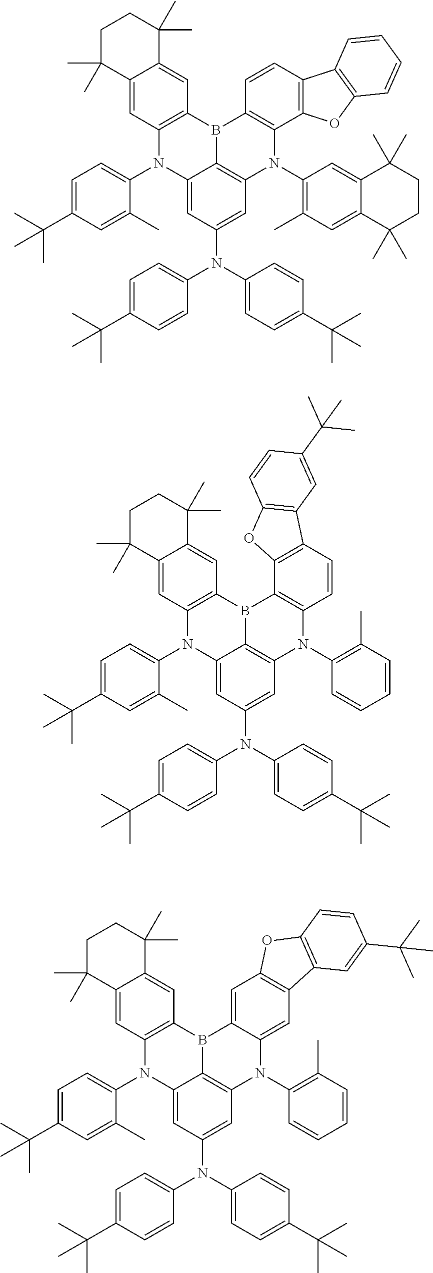

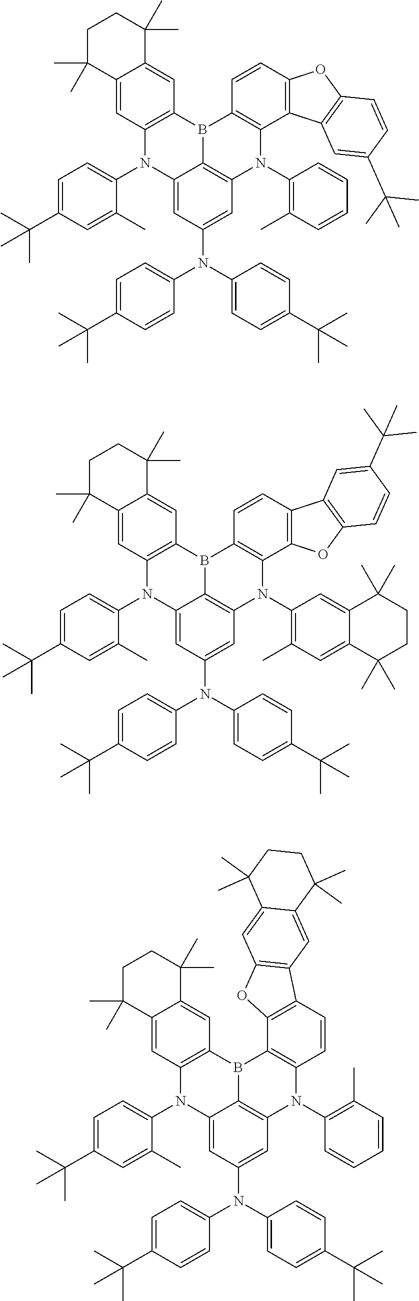

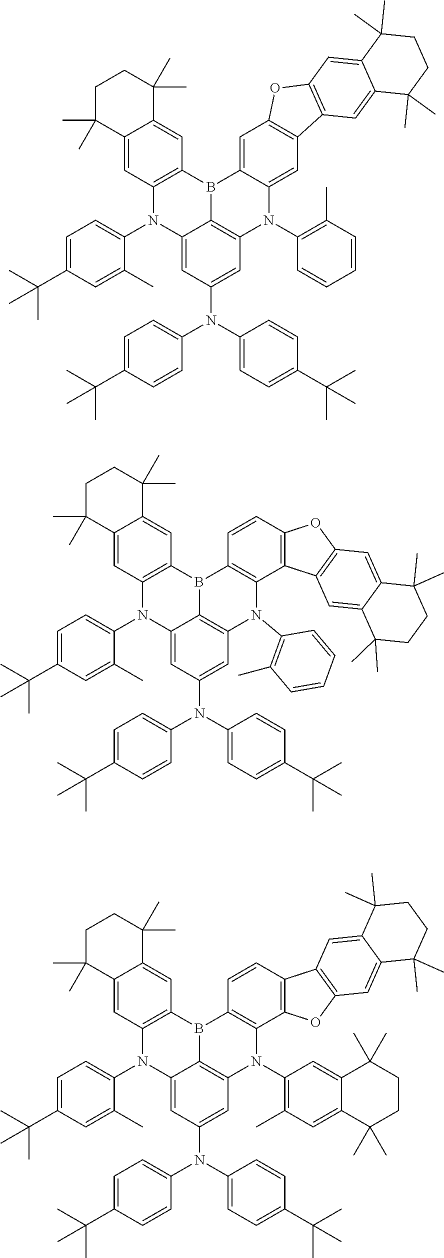

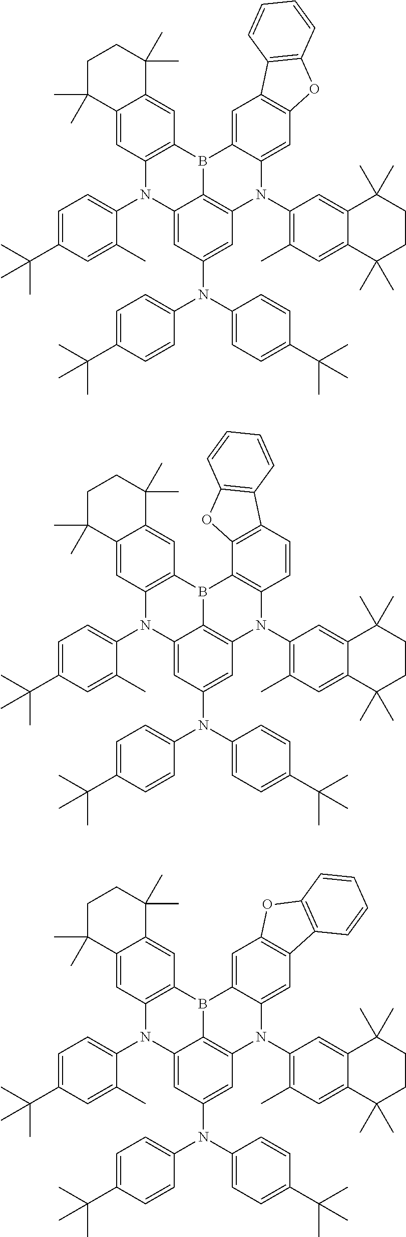 [SMILES: Cc1cc(C(C)(C)C)ccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)oc1ccccc15)C(C)(C)CCC3(C)C ; Cc1cc(C(C)(C)C)ccc1N1c2cc3c(cc2B2c4c1cc(N(c1ccc(C(C)(C)C)cc1)c1ccc(C(C)(C)C)cc1)cc4N(c1cc4c(cc1C)C(C)(C)CCC4(C)C)c1ccc4c(oc5ccccc54)c12)C(C)(C)CCC3(C)C ; Cc1cc(C(C)(C)C)ccc1N1c2cc3c(cc2B2c4cc5oc6ccccc6c5cc4N(c4cc5c(cc4C)C(C)(C)CCC5(C)C)c4cc(N(c5ccc(C(C)(C)C)cc5)c5ccc(C(C)(C)C)cc5)cc1c42)C(C)(C)CCC3(C)C]

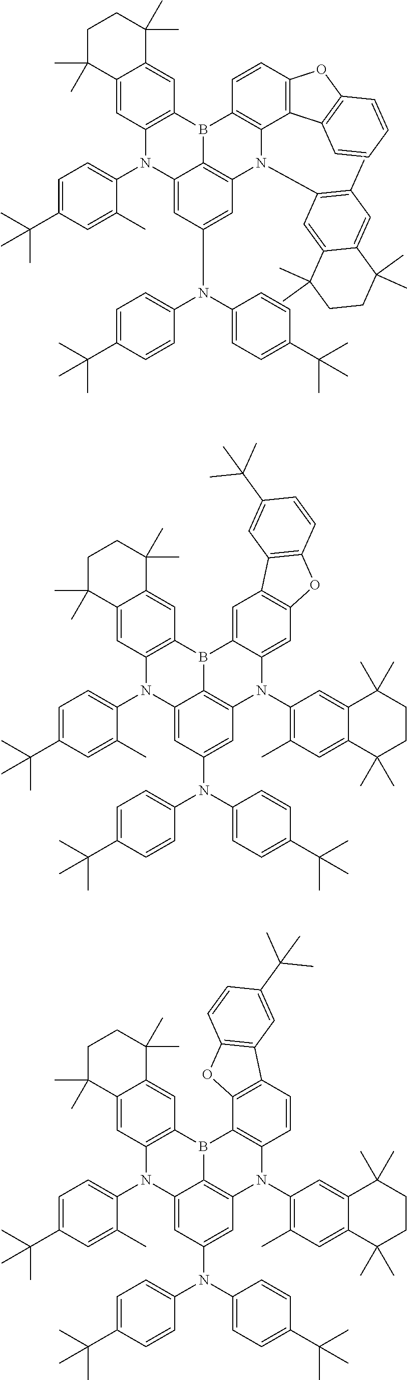

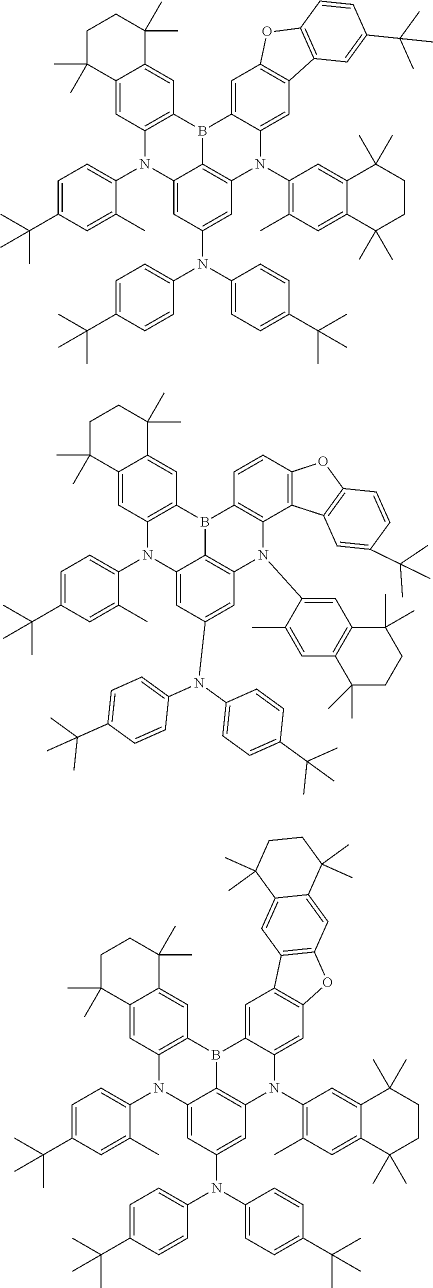

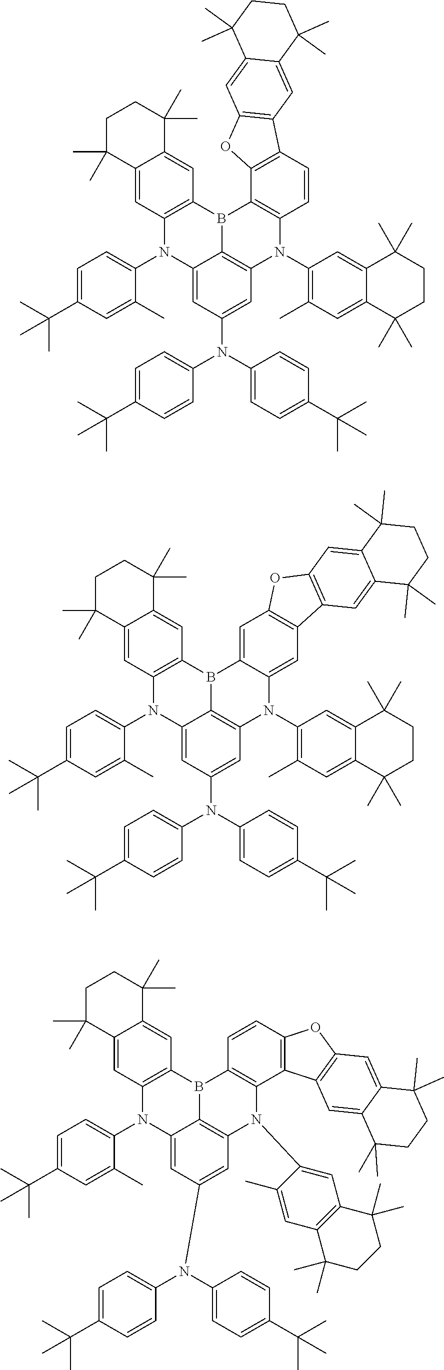

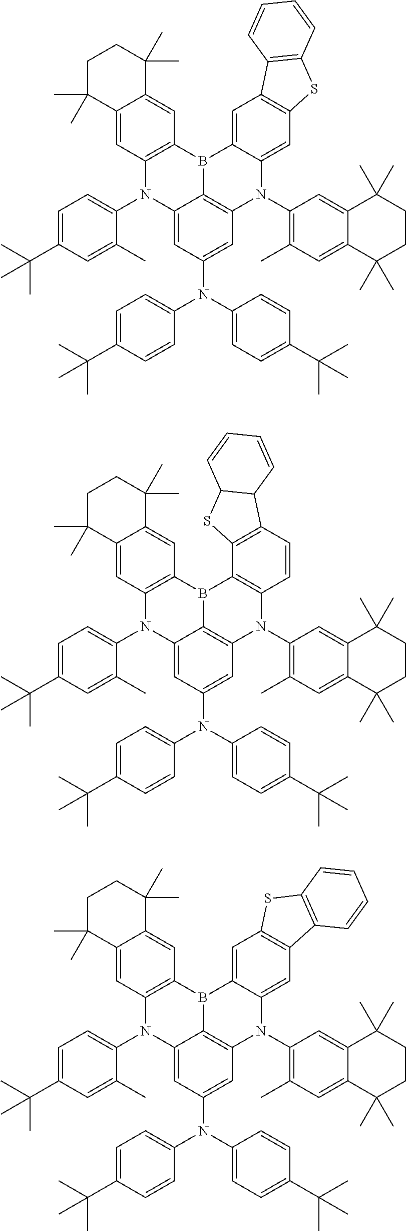

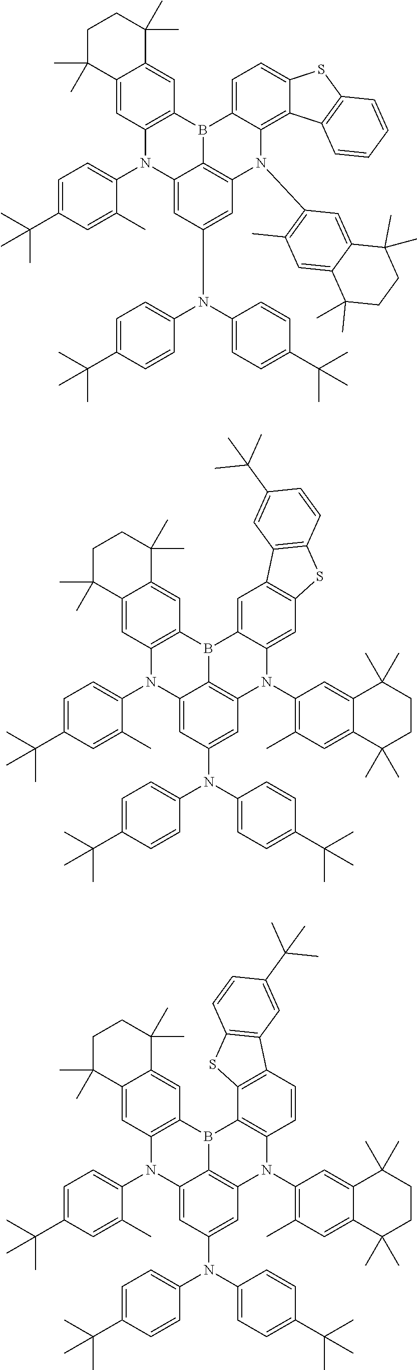

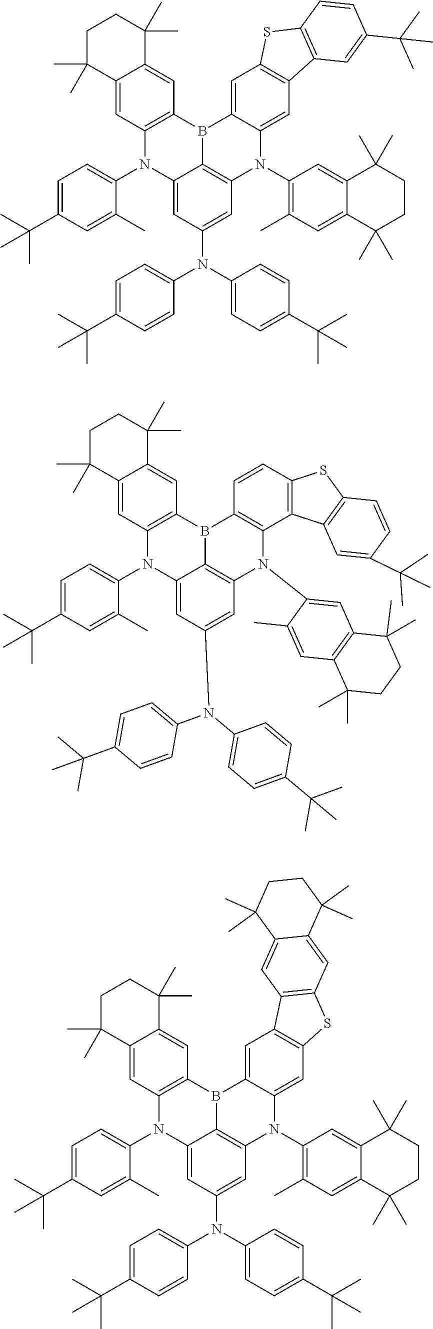

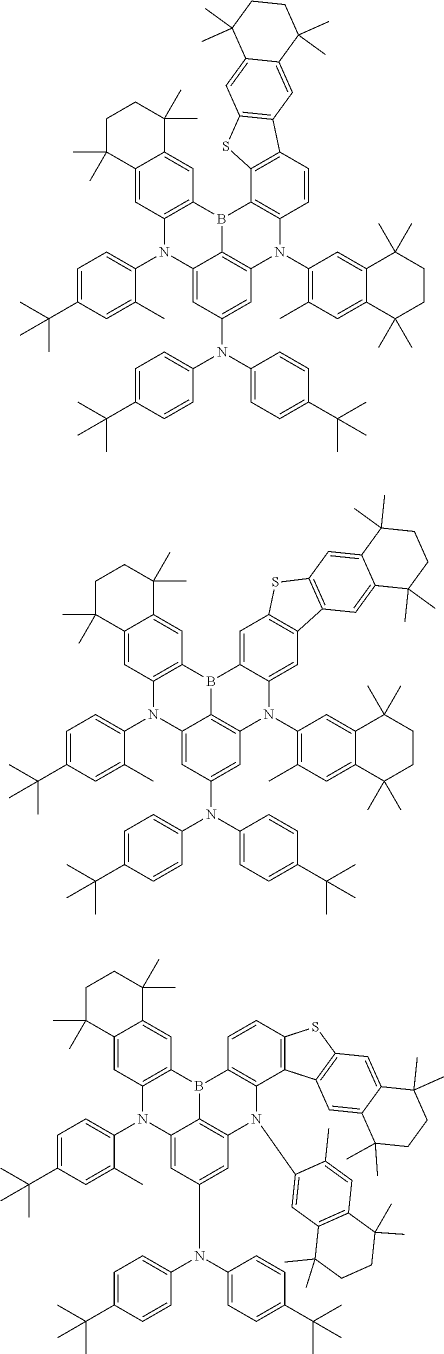

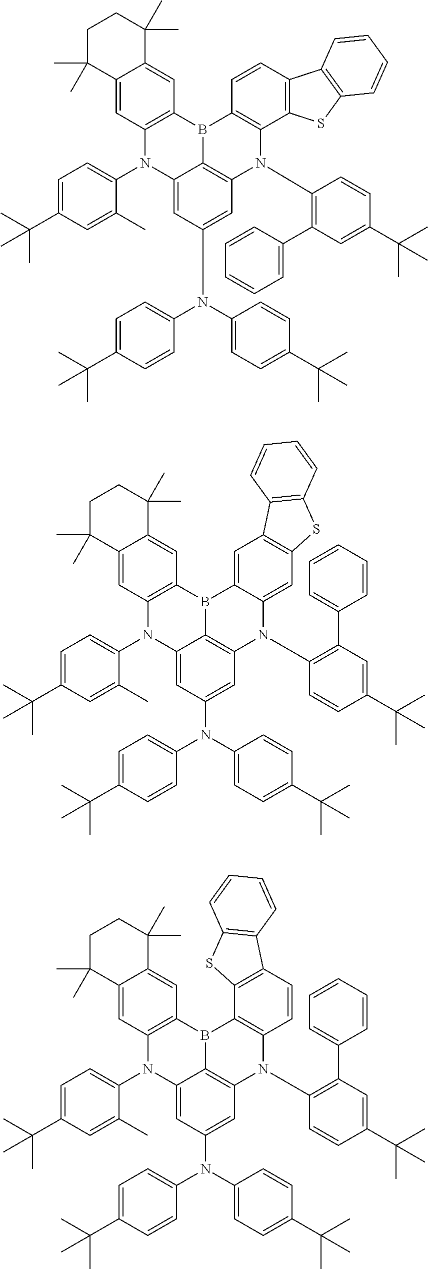

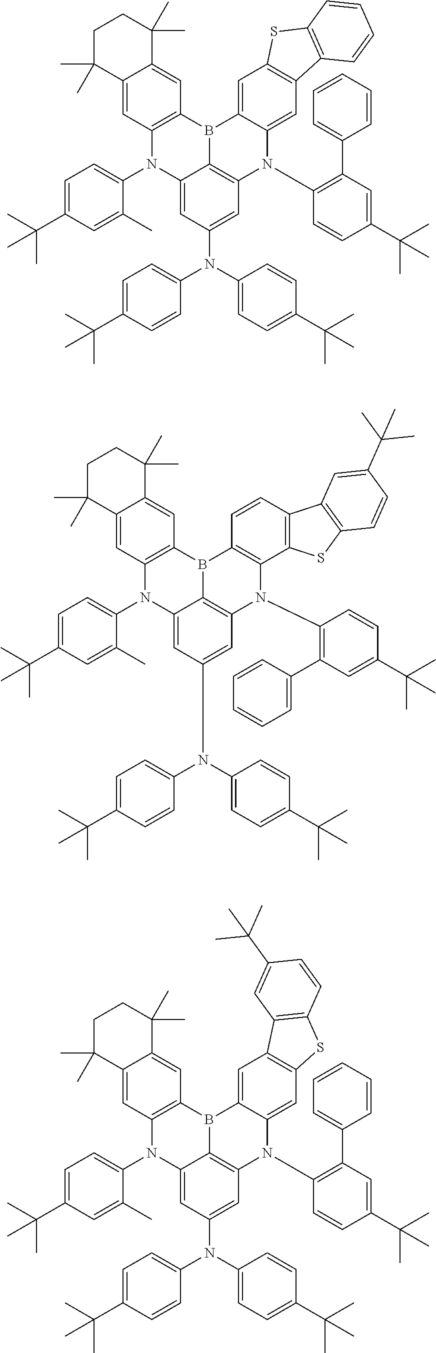

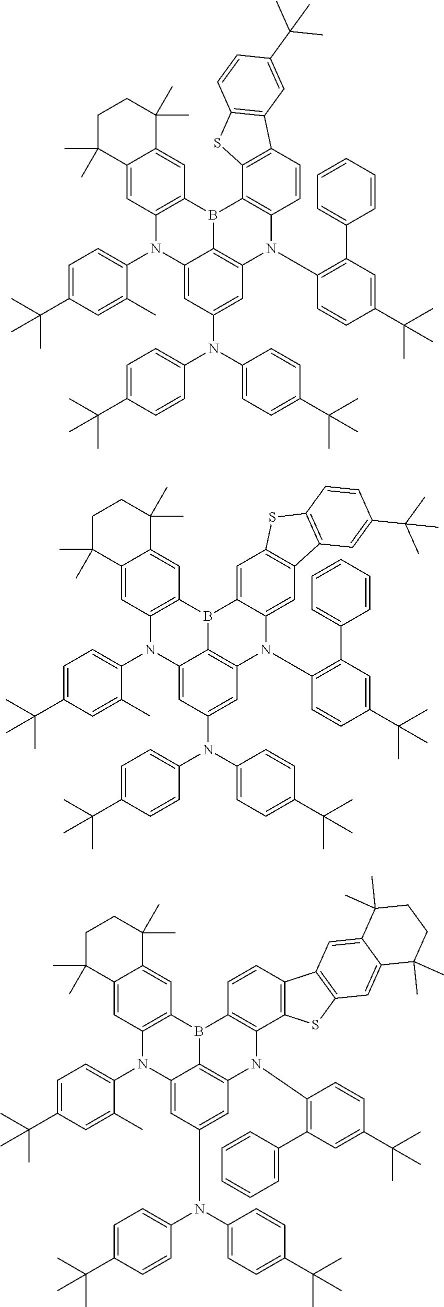

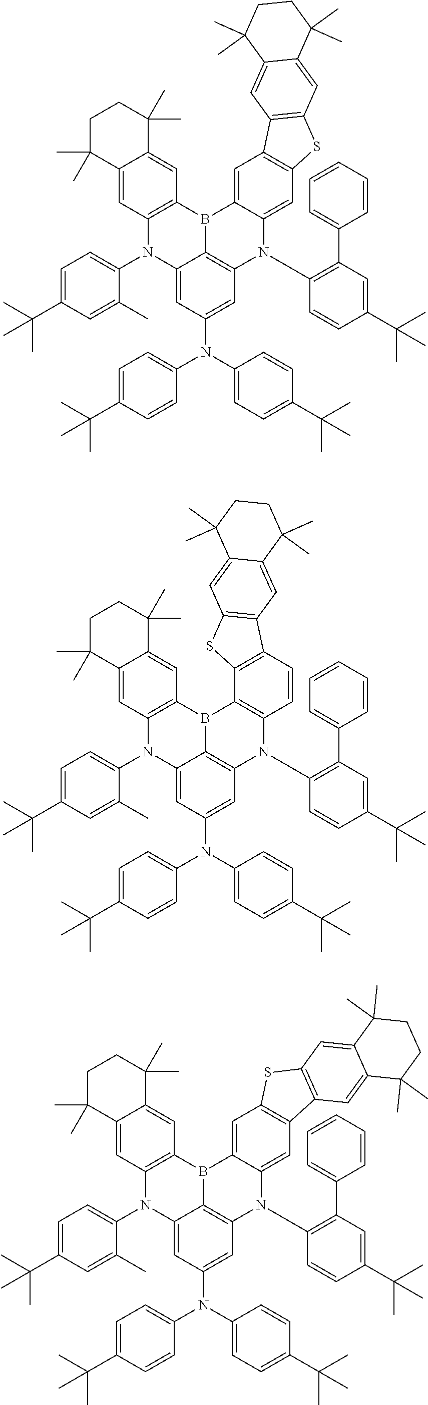

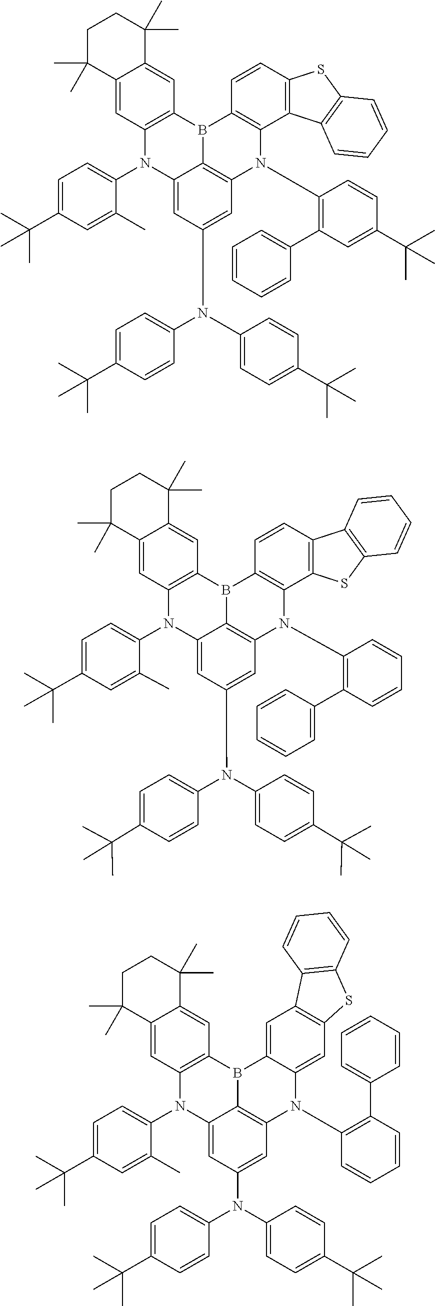

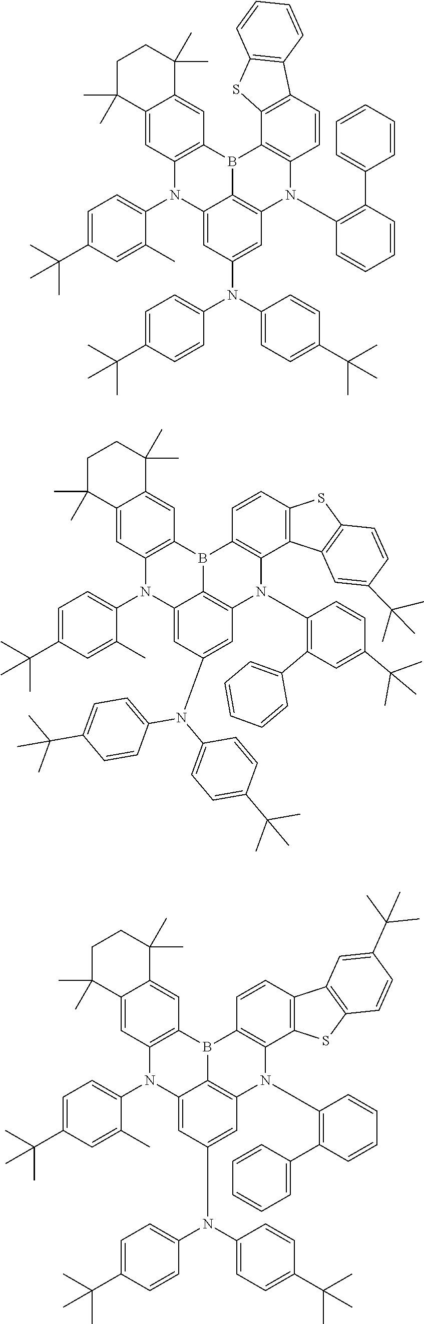

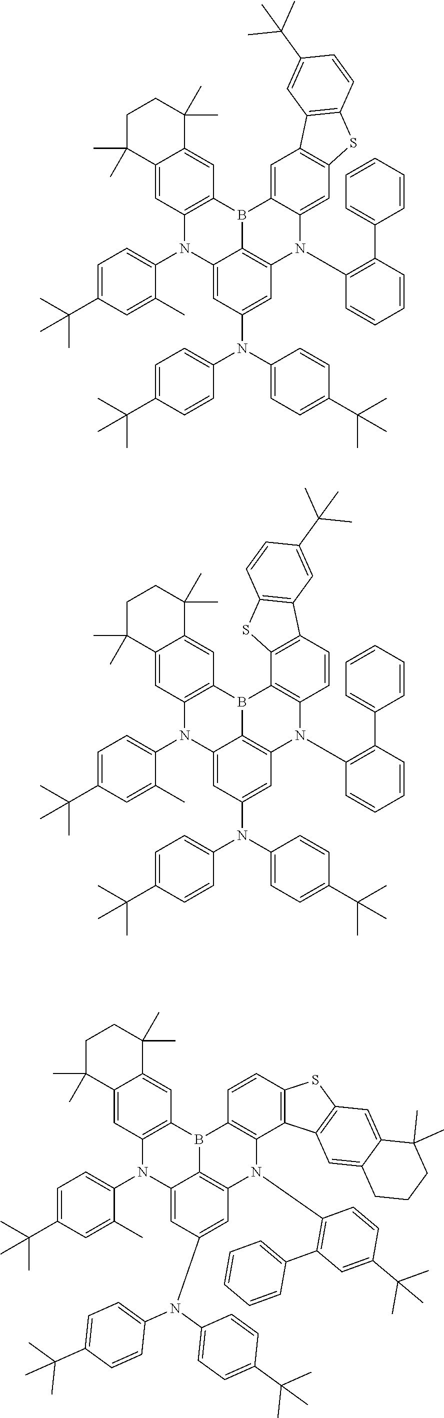 [SMILES: Cc1cc(C(C)(C)C)ccc1N1c2cc3c(cc2B2c4cc5c(cc4N(c4ccccc4-c4ccccc4)c4cc(N(c6ccc(C(C)(C)C)cc6)c6ccc(C(C)(C)C)cc6)cc1c42)sc1ccc(C(C)(C)C)cc15)C(C)(C)CCC3(C)C ; Cc1cc(C(C)(C)C)ccc1N1c2cc3c(cc2B2c4c1cc(N(c1ccc(C(C)(C)C)cc1)c1ccc(C(C)(C)C)cc1)cc4N(c1ccccc1-c1ccccc1)c1ccc4c(sc5ccc(C(C)(C)C)cc54)c12)C(C)(C)CCC3(C)C ; Cc1cc(C(C)(C)C)ccc1N1c2cc3c(cc2B2c4ccc5sc6cc7c(cc6c5c4N(c4ccc(C(C)(C)C)cc4-c4ccccc4)c4cc(N(c5ccc(C(C)(C)C)cc5)c5ccc(C(C)(C)C)cc5)cc1c42)CCCC7(C)C)C(C)(C)CCC3(C)C]

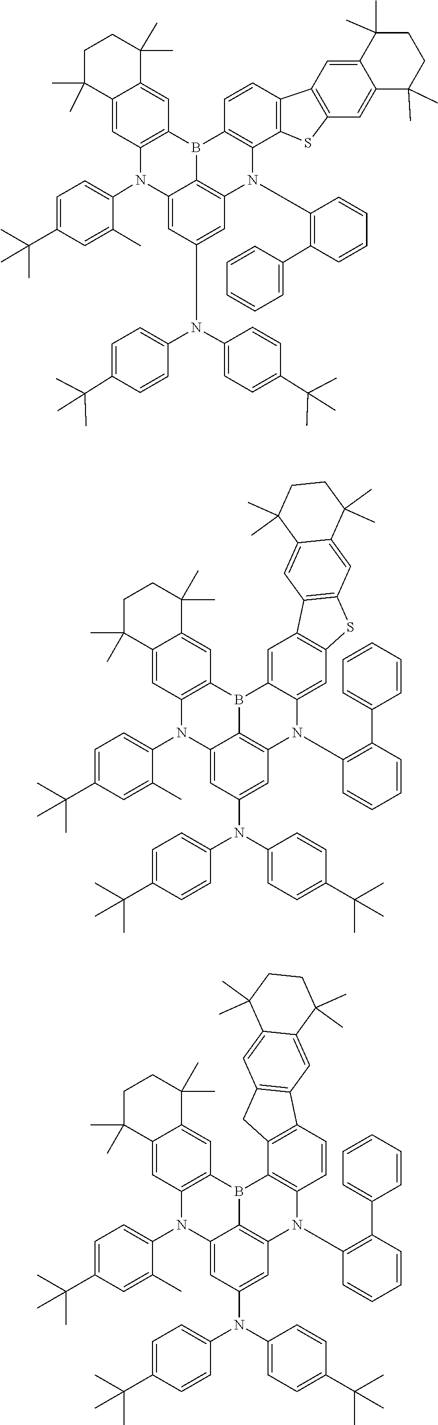

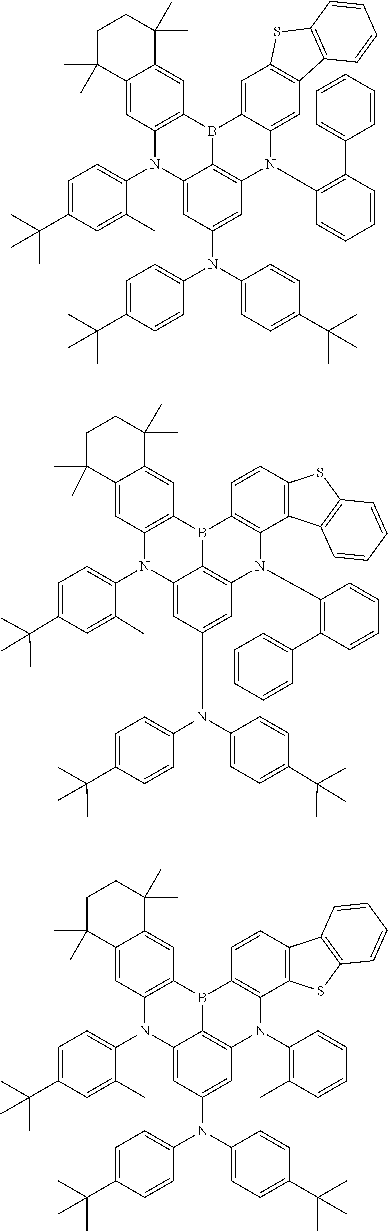 [SMILES: Cc1cc(C(C)(C)C)ccc1N1c2cc3c(cc2B2c4cc5sc6ccccc6c5cc4N(c4ccccc4-c4ccccc4)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4ccc5sc6ccccc6c5c4N(c4ccccc4-c4ccccc4)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4ccc5c(sc6ccccc65)c4N(c4ccccc4C)c4cc(N(c5ccc(C(C)(C)C)cc5)c5ccc(C(C)(C)C)cc5)cc1c42)C(C)(C)CCC3(C)C]

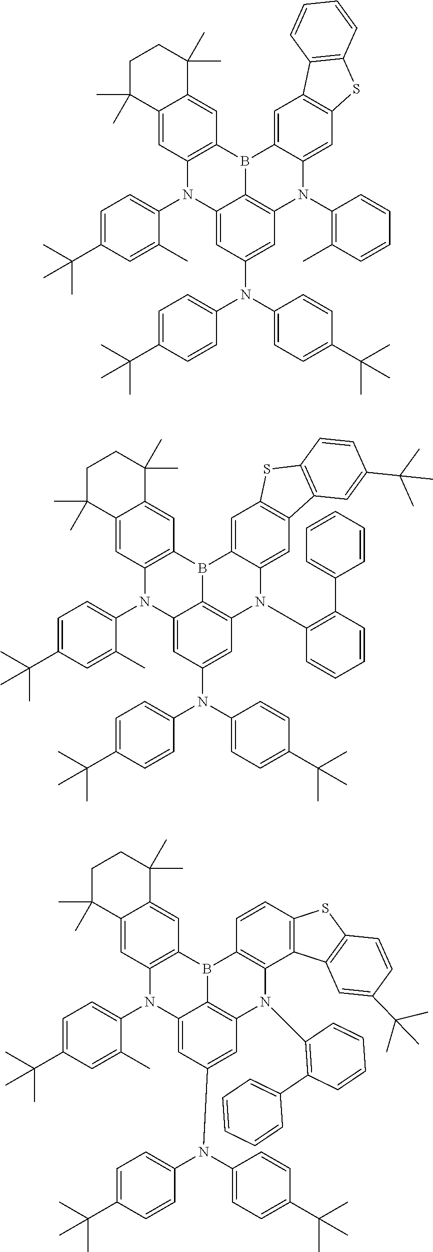

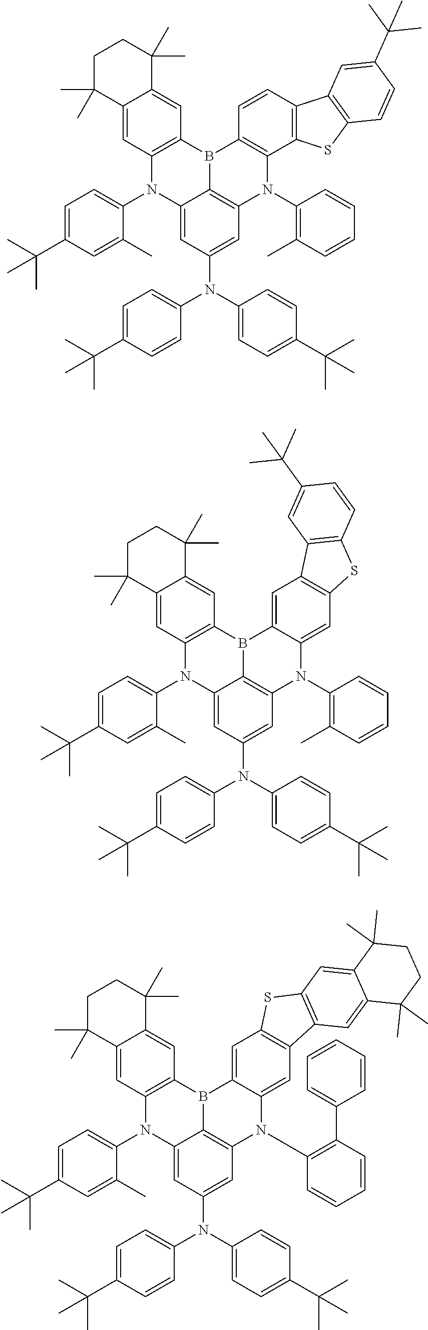

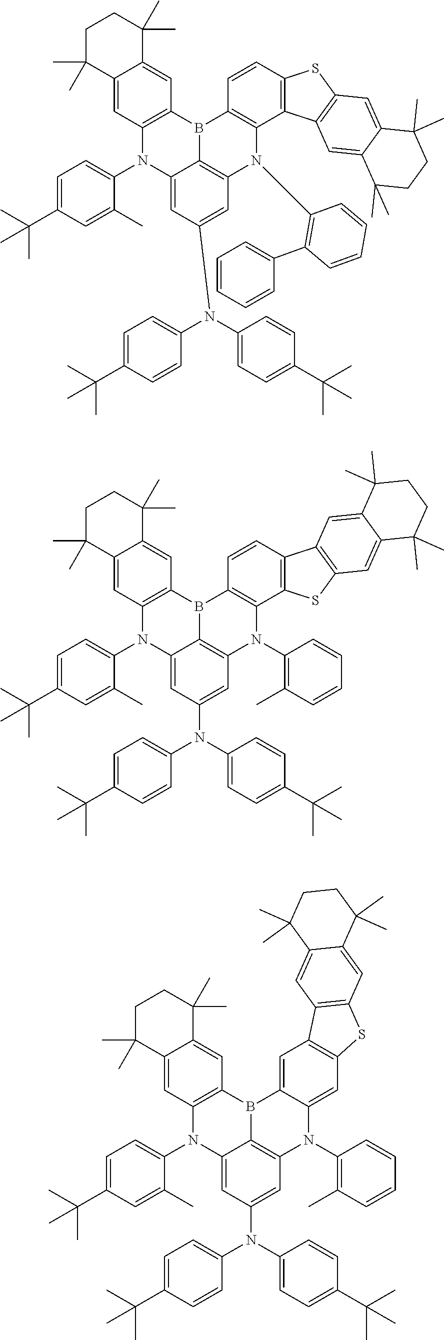

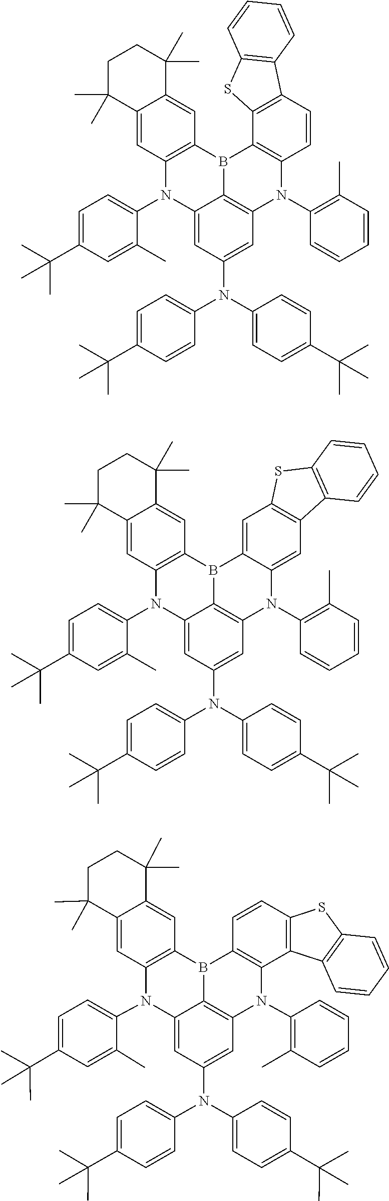

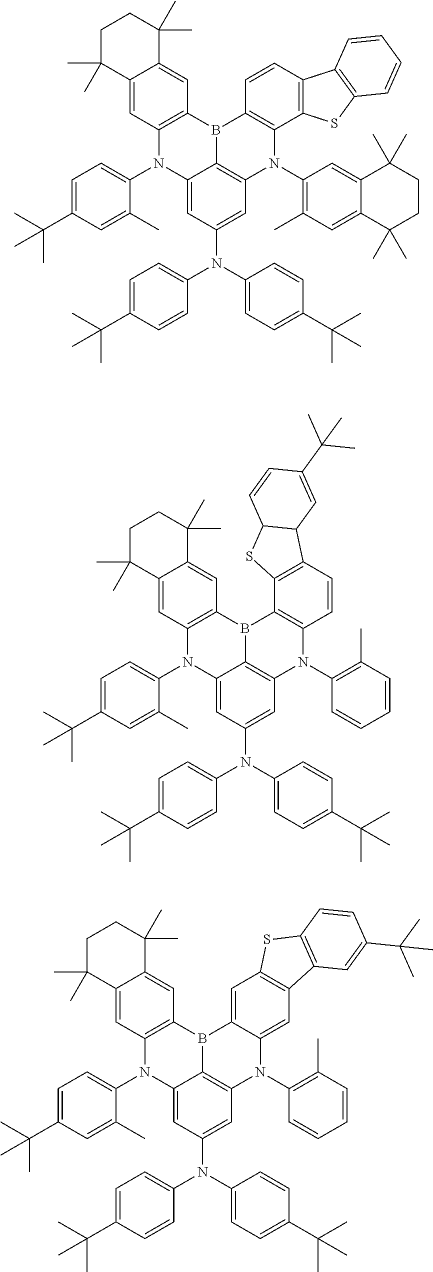 [SMILES: Cc1cc(C(C)(C)C)ccc1N1c2cc3c(cc2B2c4ccc5c(sc6ccccc65)c4N(c4cc5c(cc4C)C(C)(C)CCC5(C)C)c4cc(N(c5ccc(C(C)(C)C)cc5)c5ccc(C(C)(C)C)cc5)cc1c42)C(C)(C)CCC3(C)C ; Cc1cc(C(C)(C)C)ccc1N1c2cc3c(cc2B2c4c1cc(N(c1ccc(C(C)(C)C)cc1)c1ccc(C(C)(C)C)cc1)cc4N(c1ccccc1C)c1ccc4c(c12)SC1C=CC(C(C)(C)C)=CC41)C(C)(C)CCC3(C)C ; Cc1cc(C(C)(C)C)ccc1N1c2cc3c(cc2B2c4cc5sc6ccc(C(C)(C)C)cc6c5cc4N(c4ccccc4C)c4cc(N(c5ccc(C(C)(C)C)cc5)c5ccc(C(C)(C)C)cc5)cc1c42)C(C)(C)CCC3(C)C]

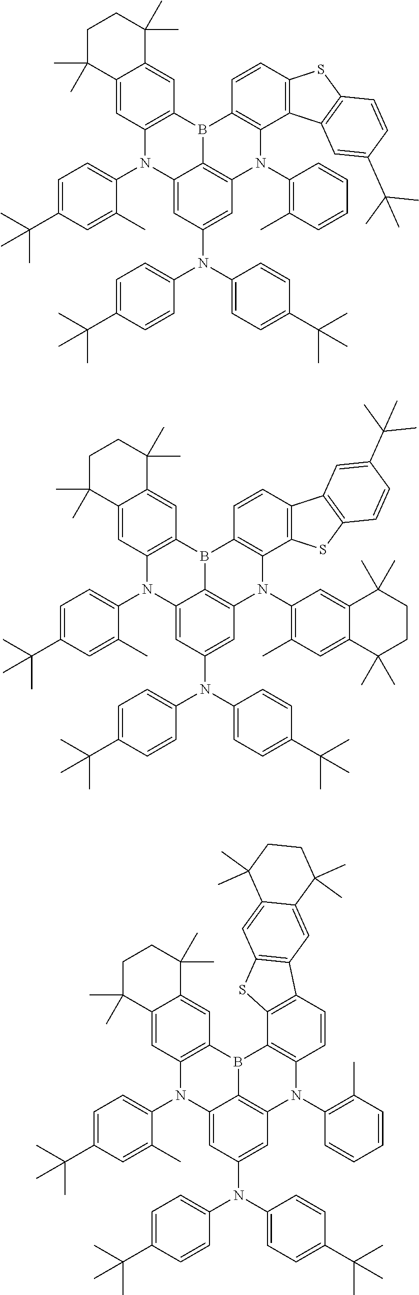

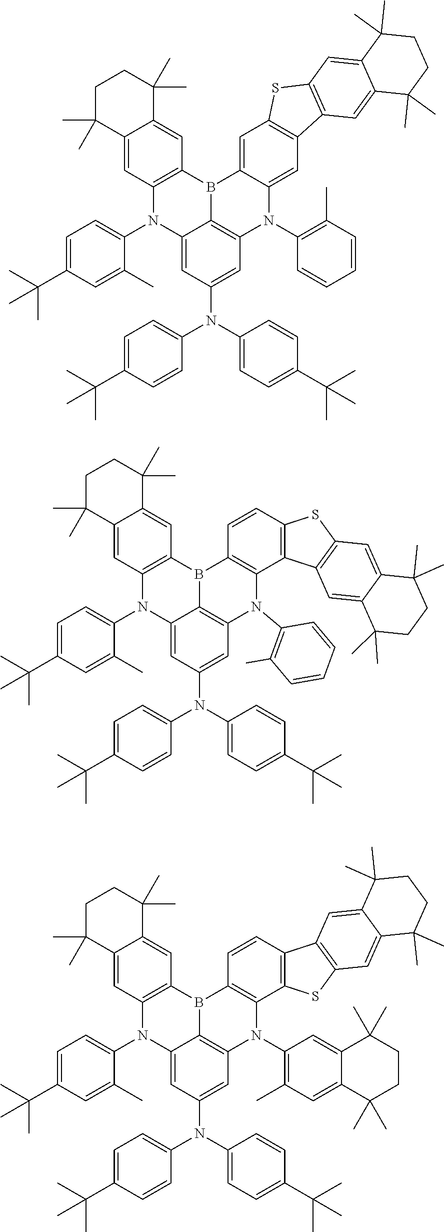

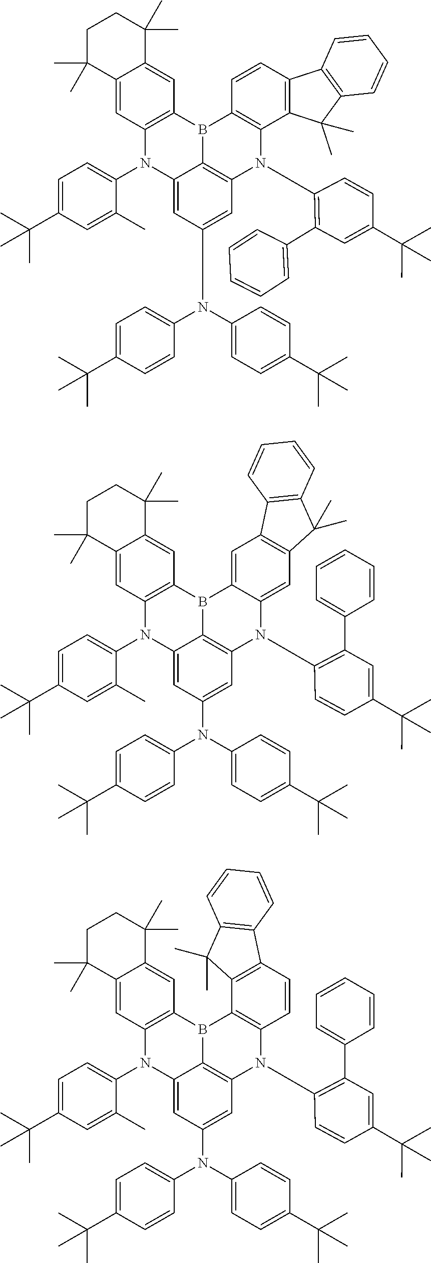

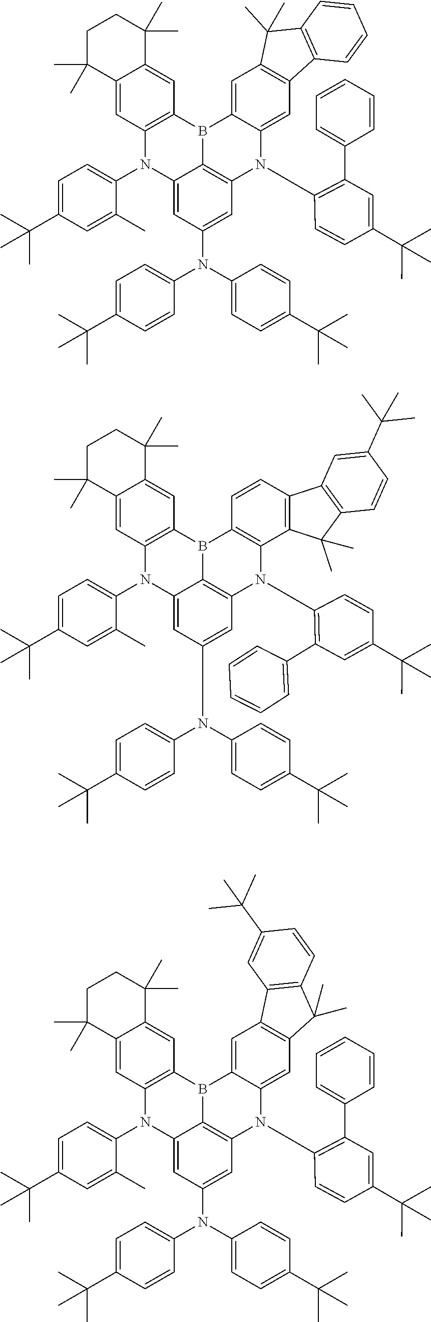

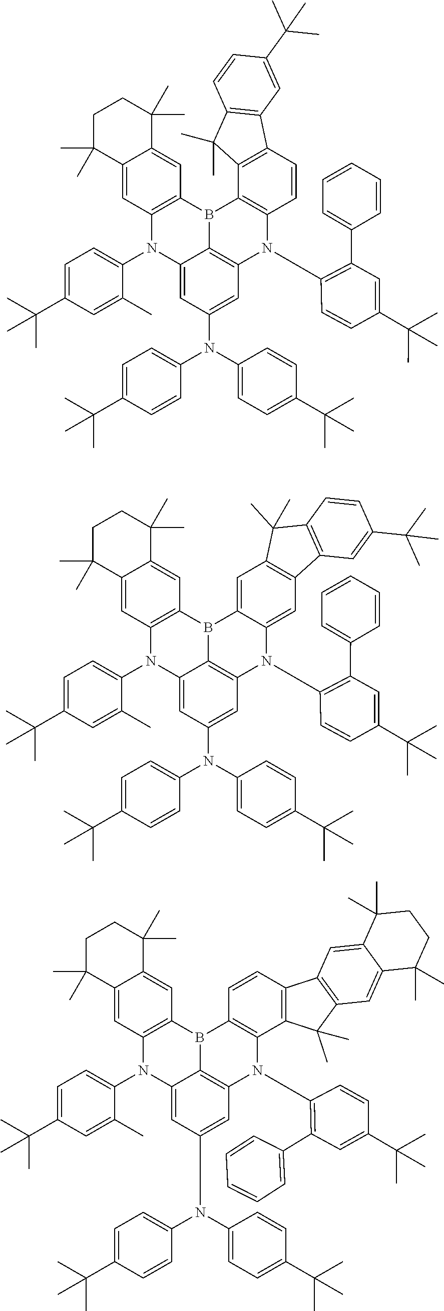

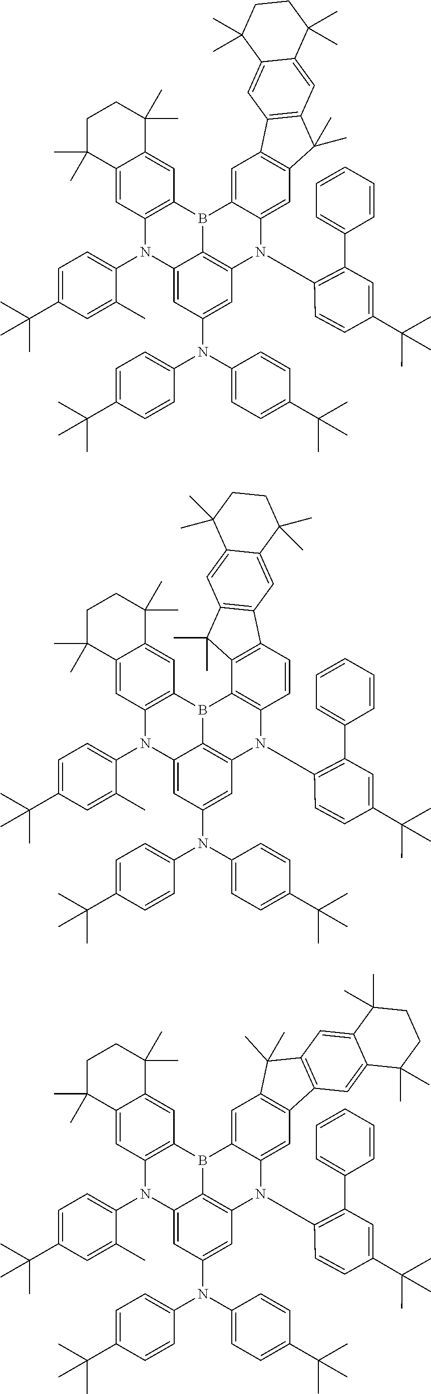

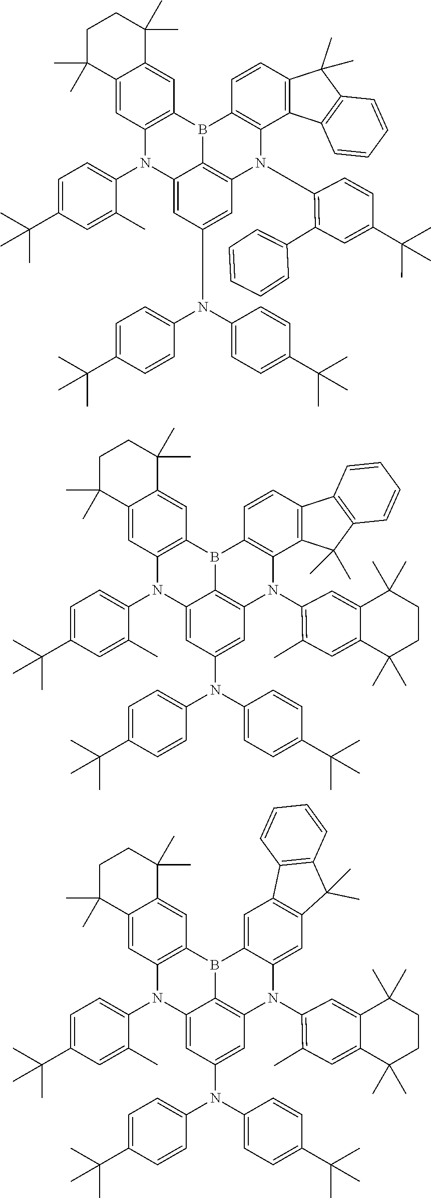

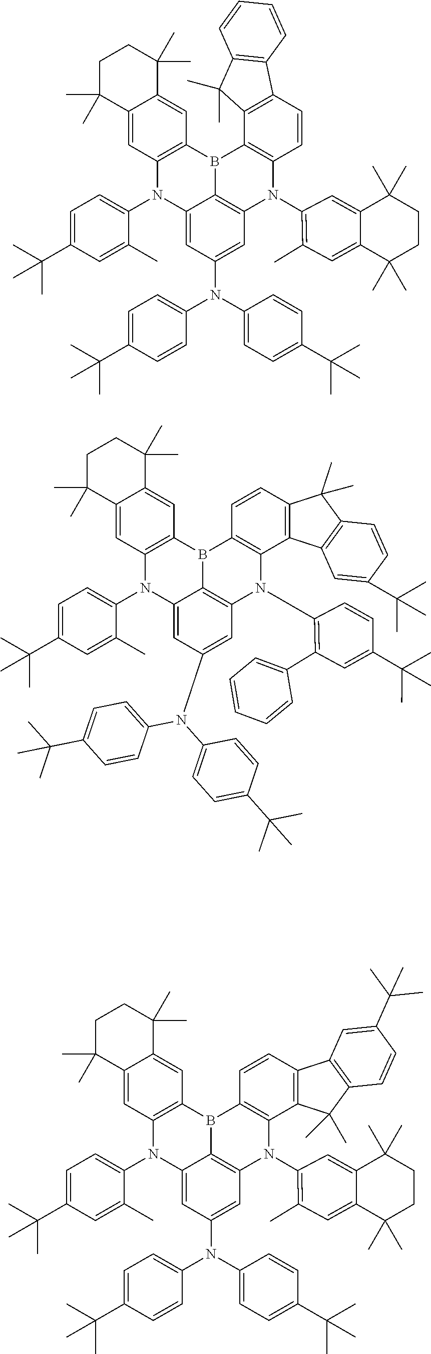

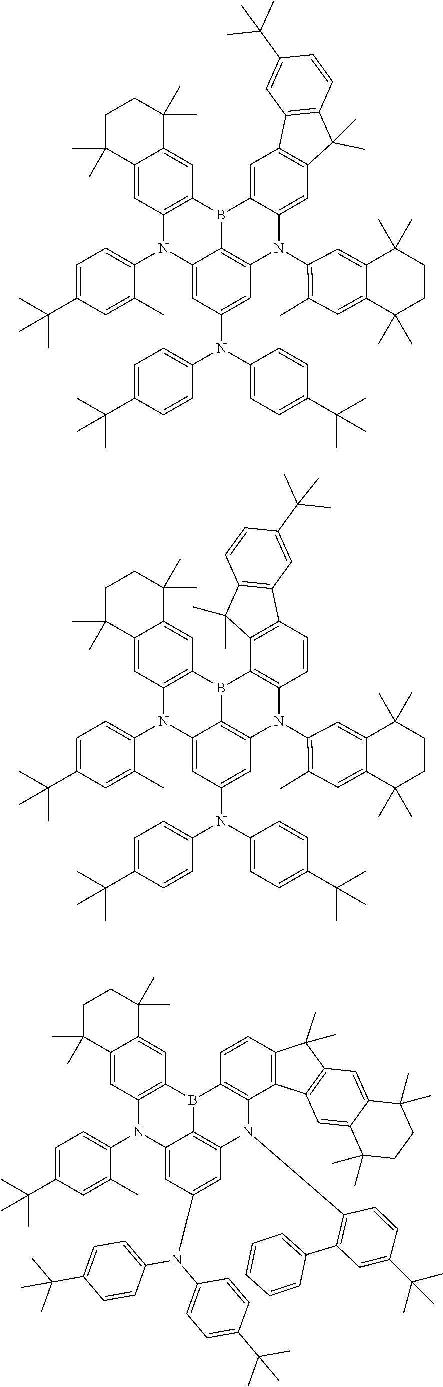

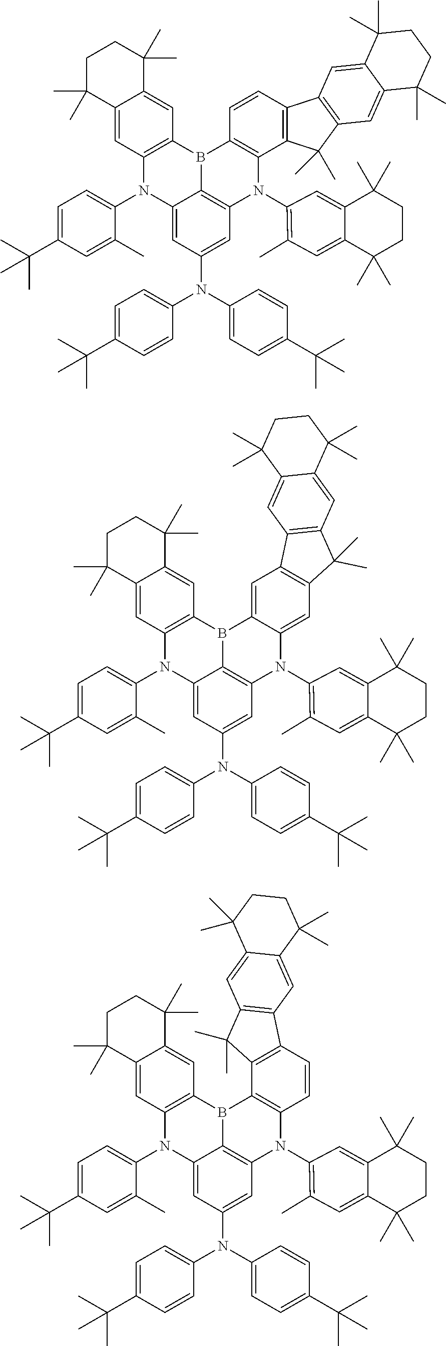

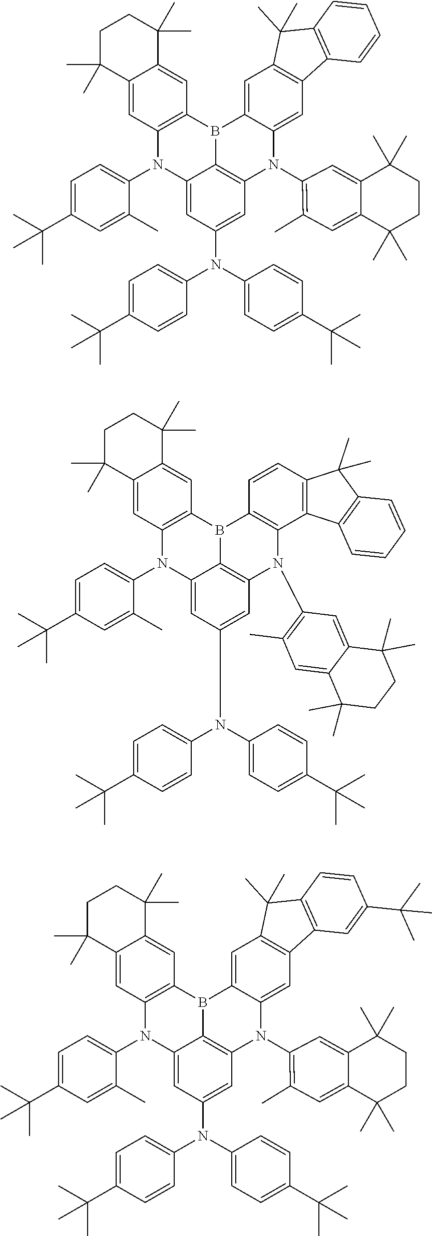

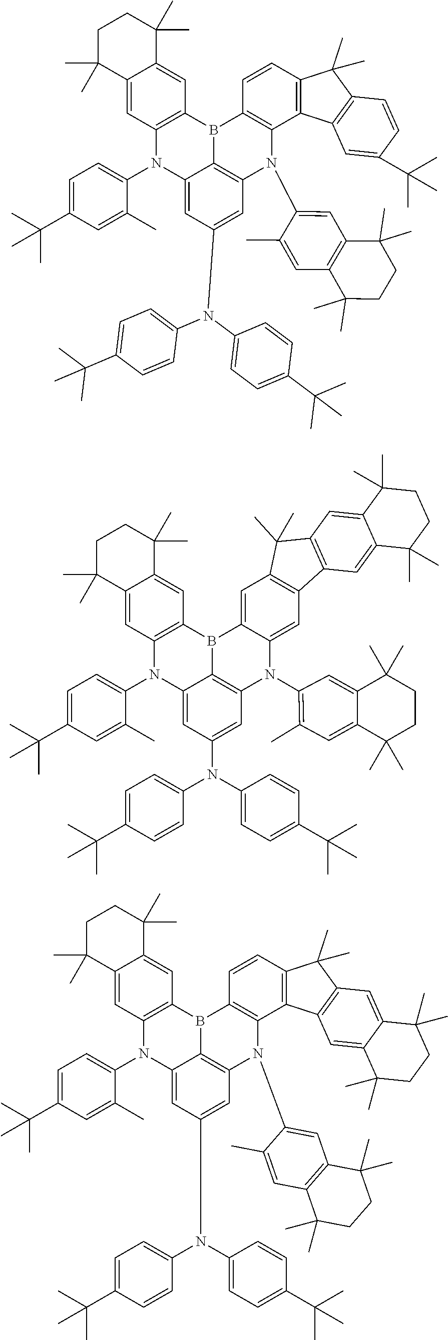

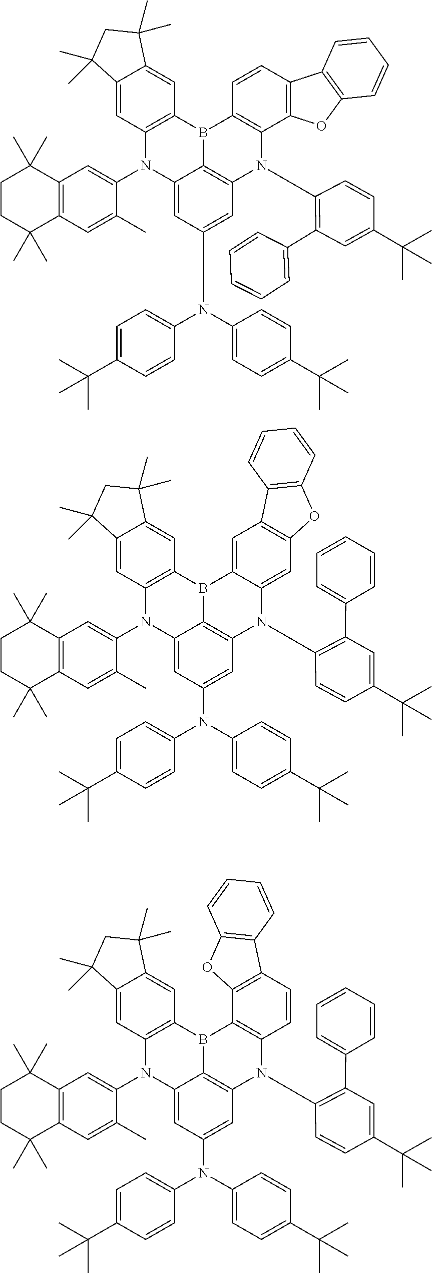

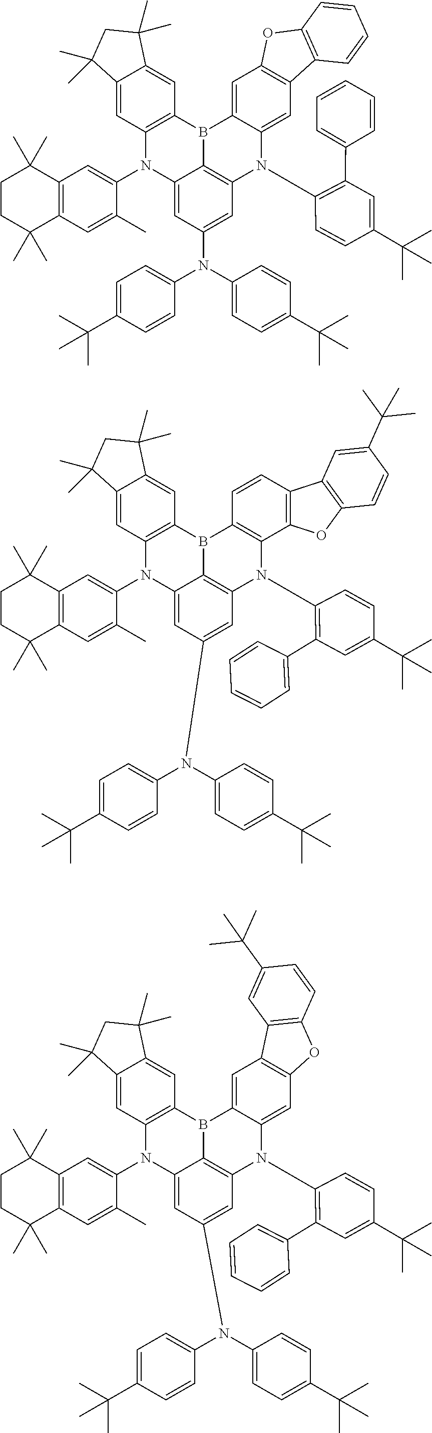

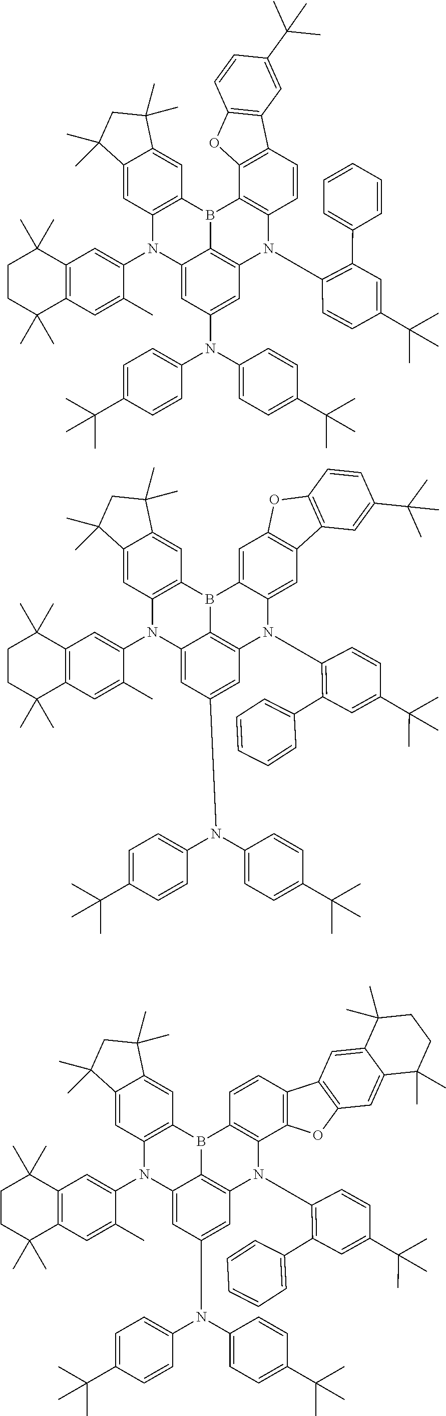

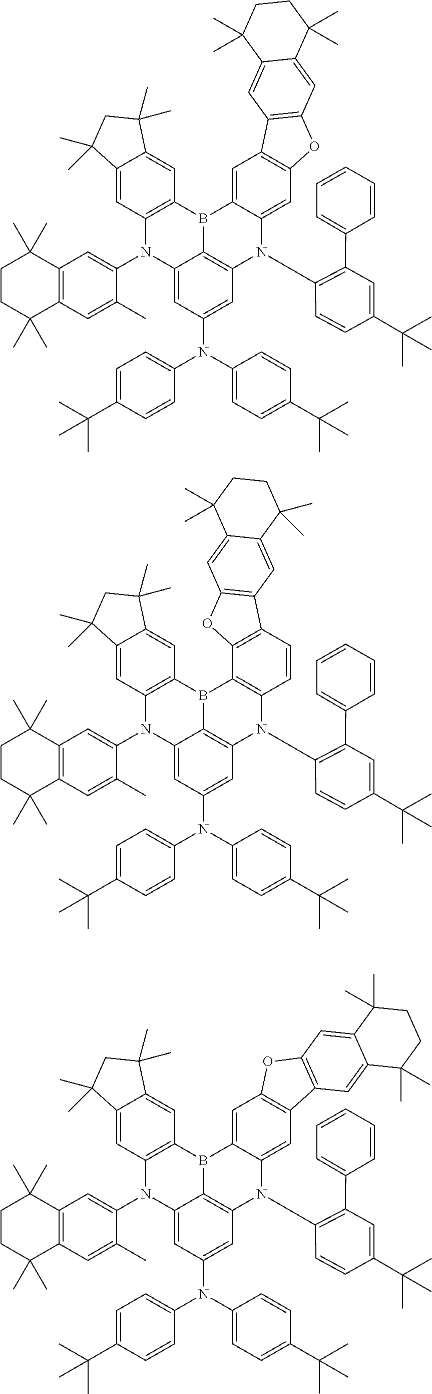

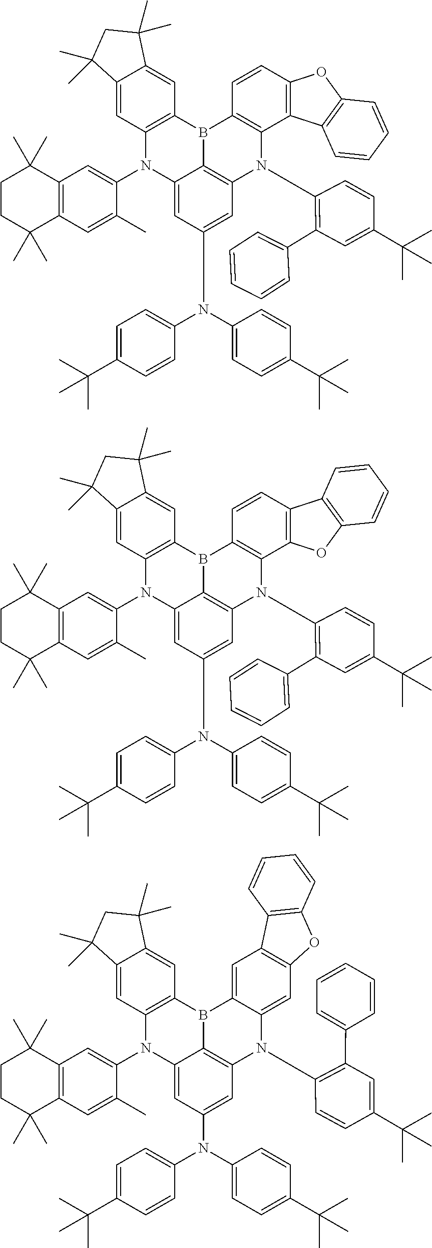

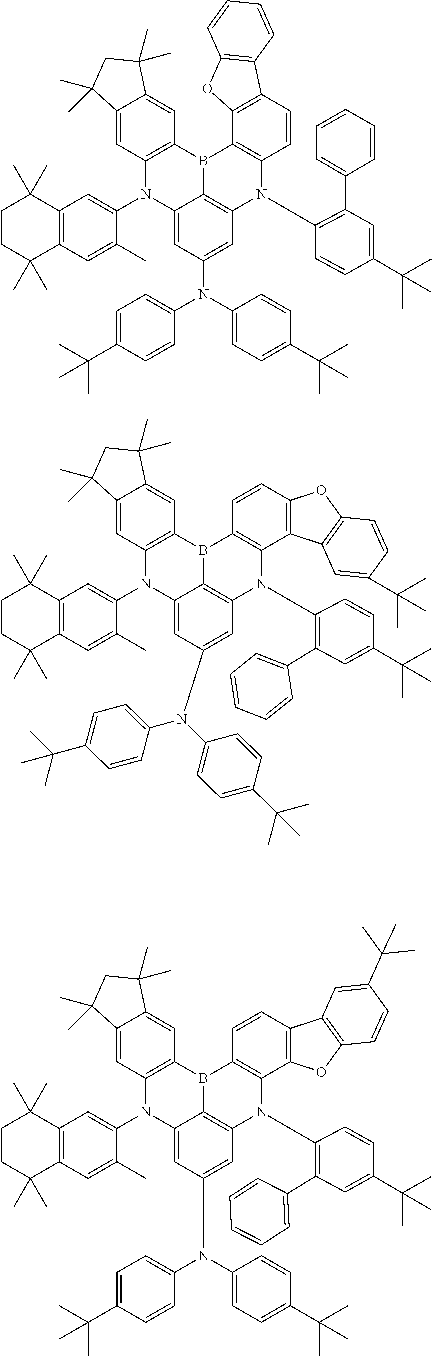 [SMILES: Cc1cc2c(cc1N1c3cc4c(cc3B3c5c1cc(N(c1ccc(C(C)(C)C)cc1)c1ccc(C(C)(C)C)cc1)cc5N(c1ccc(C(C)(C)C)cc1-c1ccccc1)c1ccc5c(oc6ccccc65)c13)C(C)(C)CC4(C)C)C(C)(C)CCC2(C)C ; Cc1cc2c(cc1N1c3cc4c(cc3B3c5ccc6oc7ccc(C(C)(C)C)cc7c6c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C]

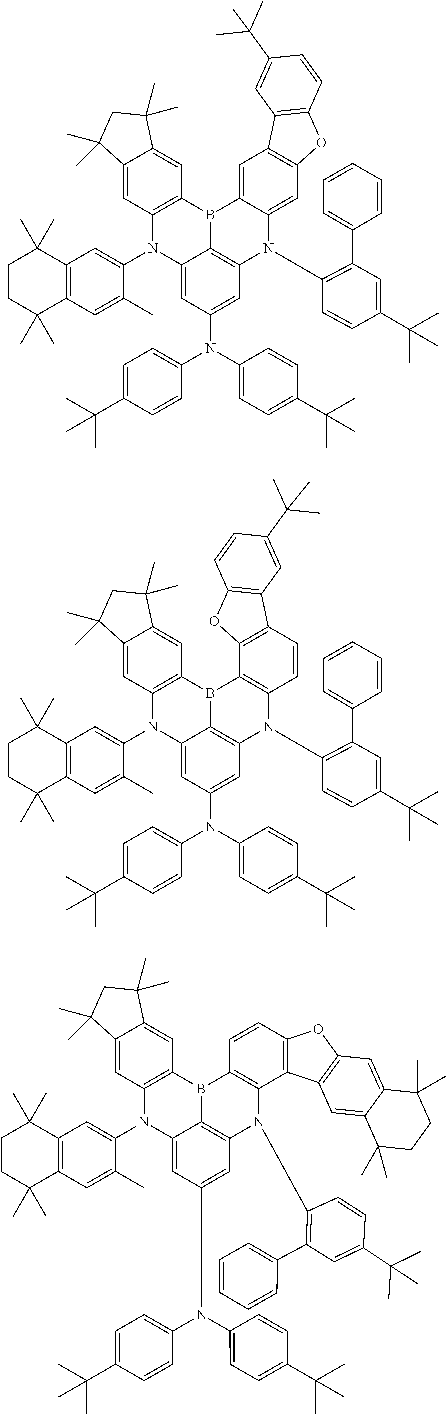

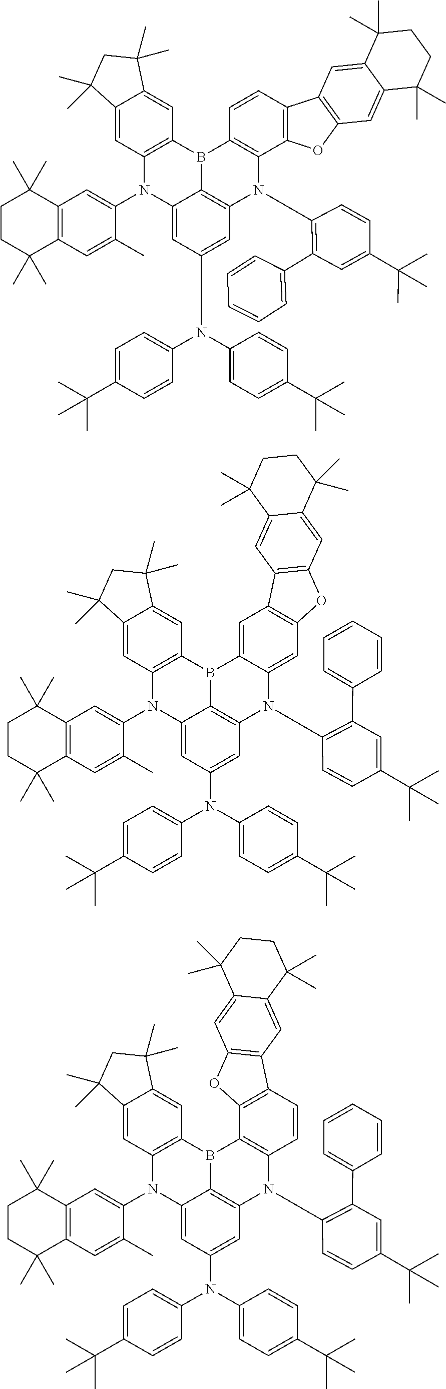

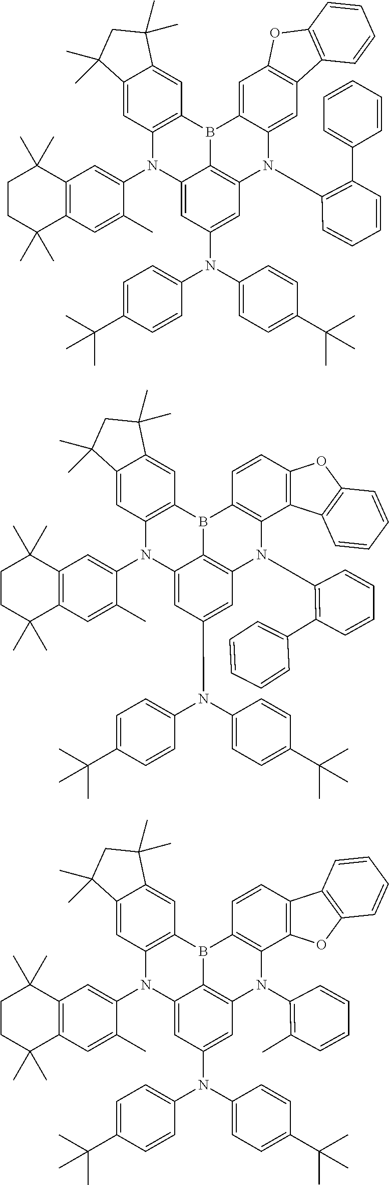 [SMILES: Cc1cc2c(cc1N1c3cc4c(cc3B3c5cc6oc7ccccc7c6cc5N(c5ccccc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6oc7ccccc7c6c5N(c5ccccc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(oc7ccccc76)c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C]

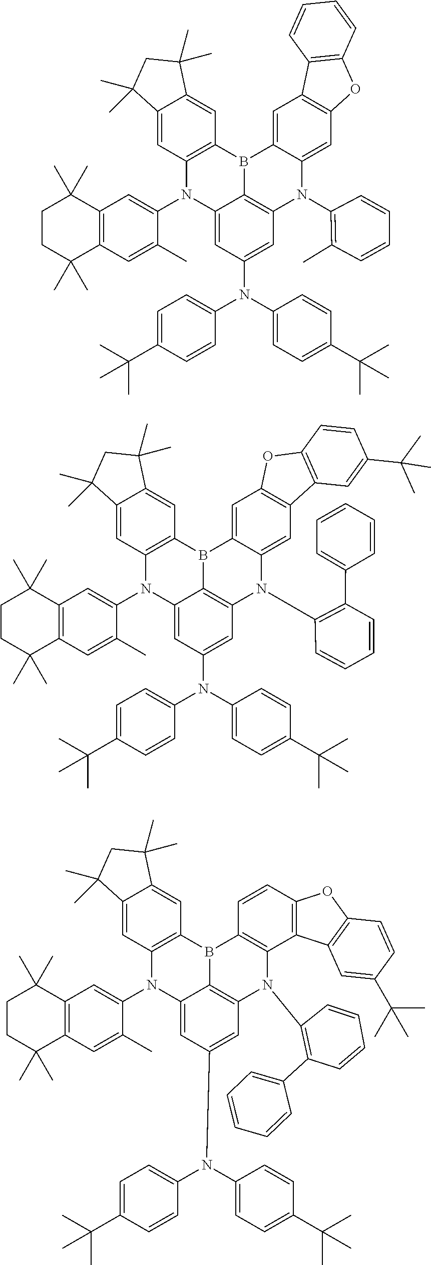

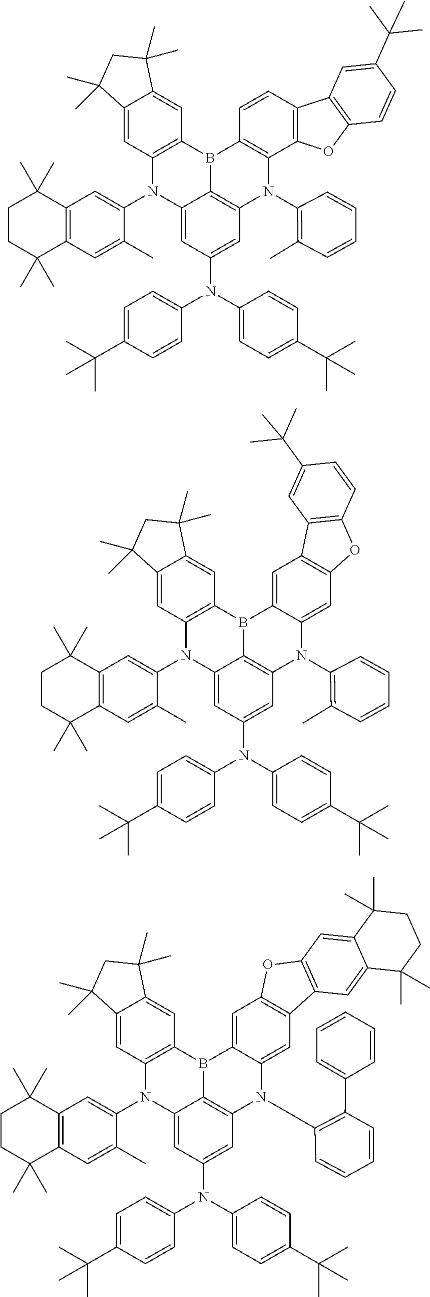

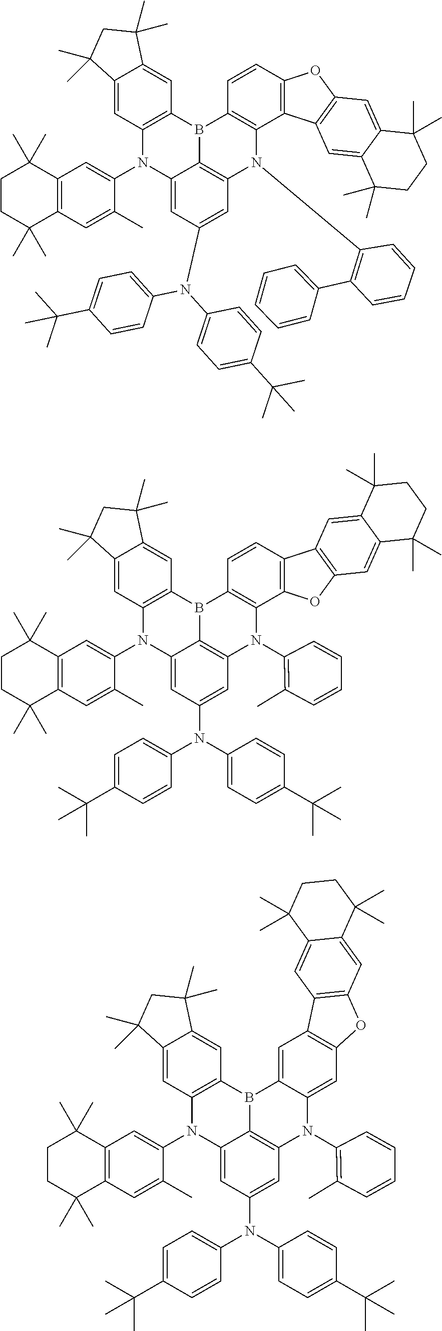 [SMILES: Cc1cc2c(cc1N1c3cc4c(cc3B3c5ccc6oc7cc8c(cc7c6c5N(c5ccccc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C ; Cc1ccccc1N1c2cc3oc4cc5c(cc4c3cc2B2c3cc4c(cc3N(c3cc6c(cc3C)C(C)(C)CCC6(C)C)c3cc(N(c6ccc(C(C)(C)C)cc6)c6ccc(C(C)(C)C)cc6)cc1c32)C(C)(C)CC4(C)C)C(C)(C)CCC5(C)C]

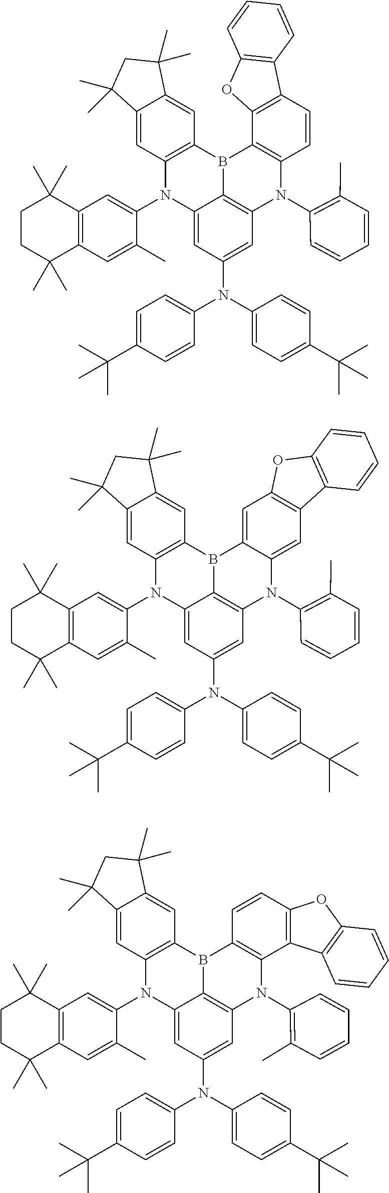

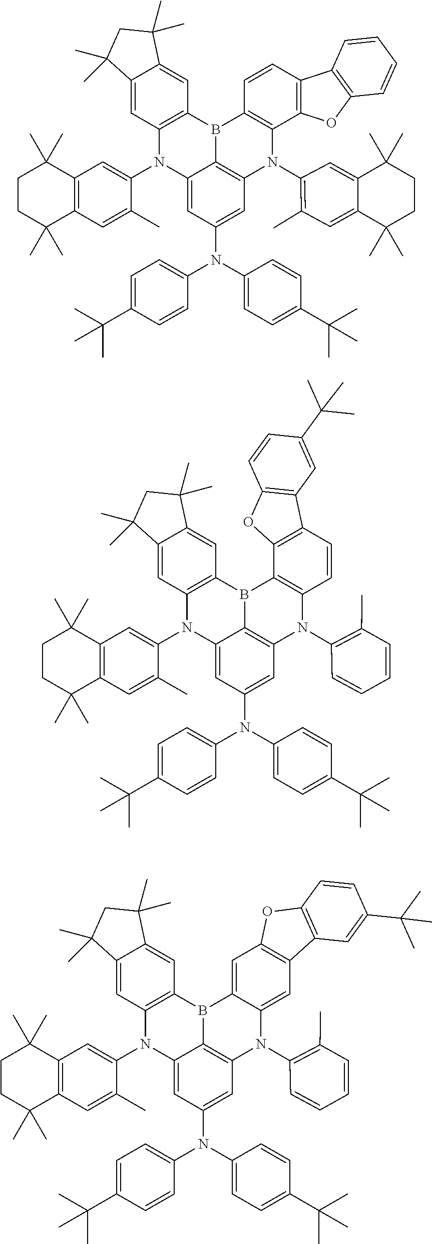

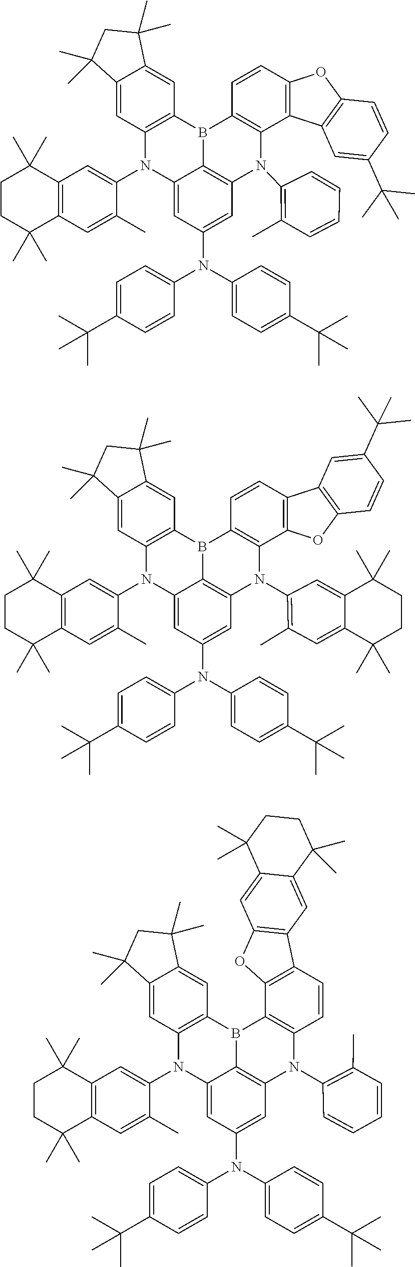 [SMILES: Cc1cc2c(cc1N1c3cc4c(cc3B3c5ccc6oc7ccc(C(C)(C)C)cc7c6c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(oc7ccc(C(C)(C)C)cc76)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccccc1C)c1ccc5c(oc6cc7c(cc65)C(C)(C)CCC7(C)C)c13)C(C)(C)CC4(C)C)C(C)(C)CCC2(C)C]

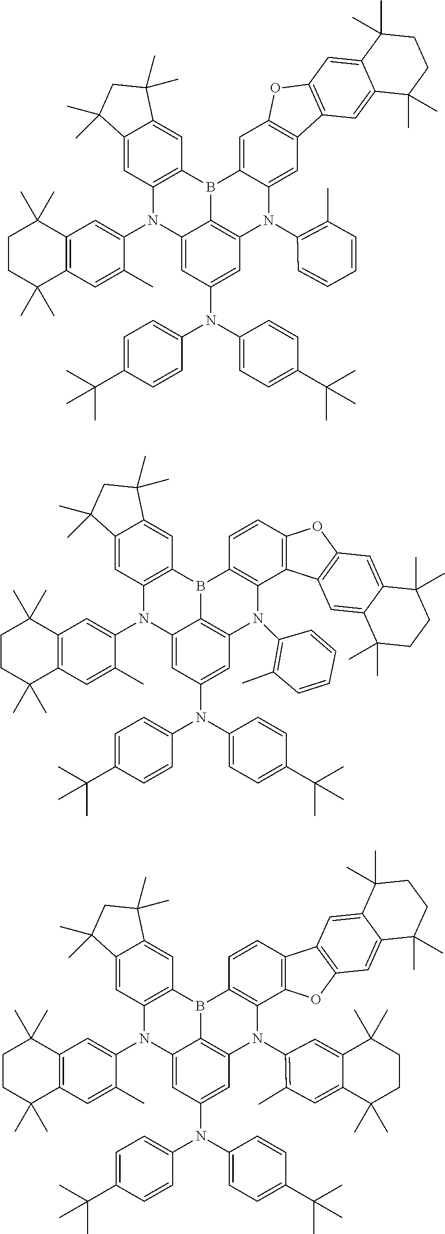 [SMILES: Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)CC5(C)C)oc1cc2c(cc13)C(C)(C)CCC2(C)C ; Cc1cc2c(cc1N1c3cc4c(cc3B3c5ccc6oc7cc8c(cc7c6c5N(c5ccccc5C)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C]

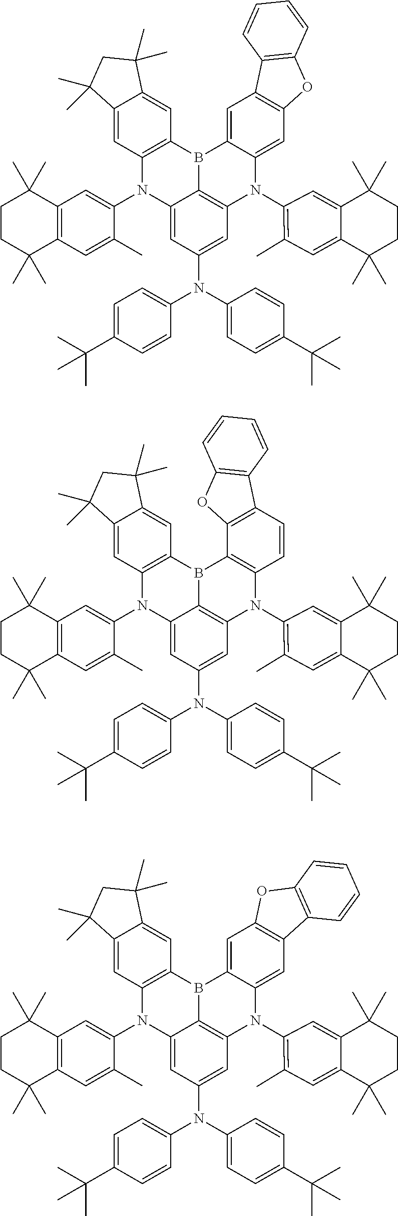 [SMILES: Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)oc1ccccc16)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1cc5c(cc1C)C(C)(C)CCC5(C)C)c1ccc5c(oc6ccccc65)c13)C(C)(C)CC4(C)C)C(C)(C)CCC2(C)C ; Cc1cc2c(cc1N1c3cc4c(cc3B3c5cc6oc7ccccc7c6cc5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C]

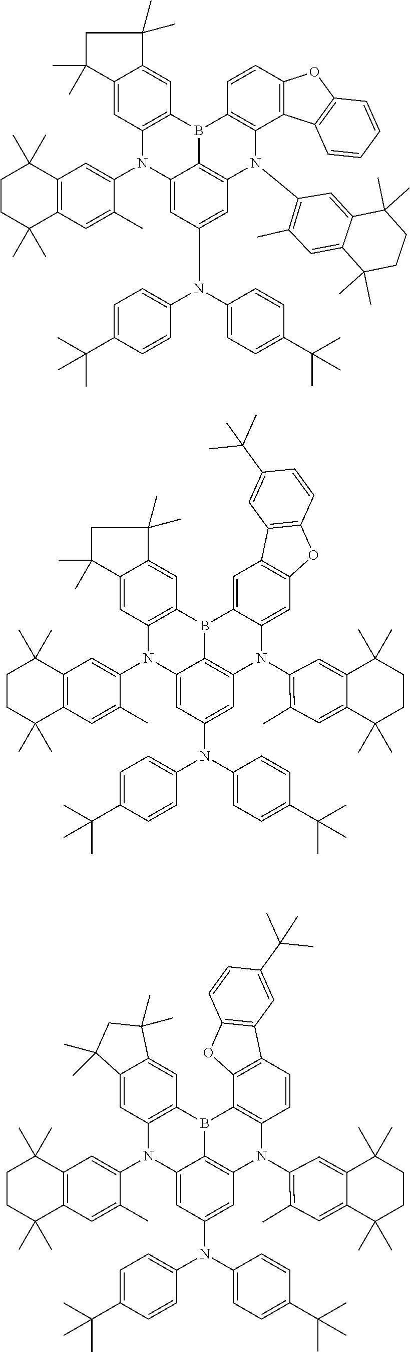 [SMILES: Cc1cc2c(cc1N1c3cc4c(cc3B3c5ccc6oc7ccccc7c6c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)oc1ccc(C(C)(C)C)cc16)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1cc5c(cc1C)C(C)(C)CCC5(C)C)c1ccc5c(oc6ccc(C(C)(C)C)cc65)c13)C(C)(C)CC4(C)C)C(C)(C)CCC2(C)C]

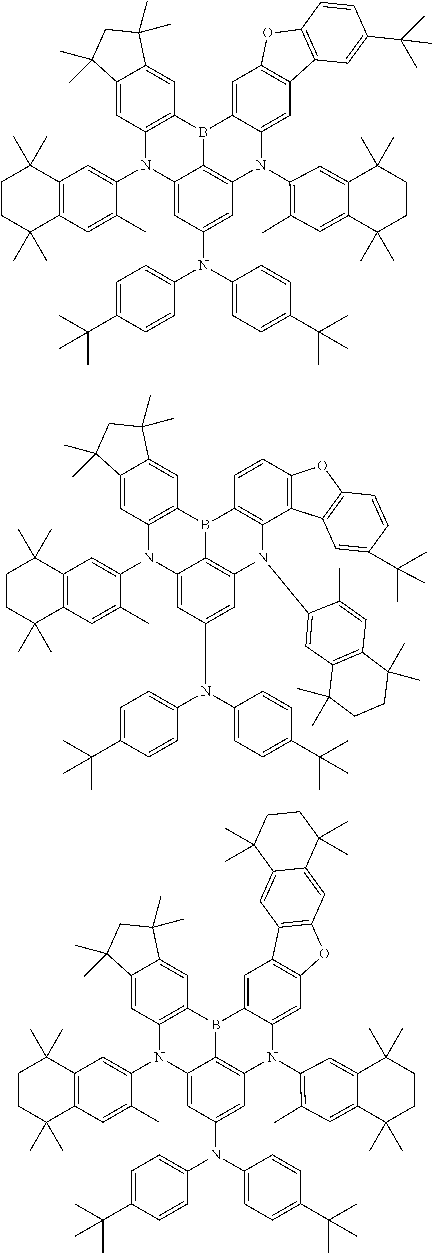

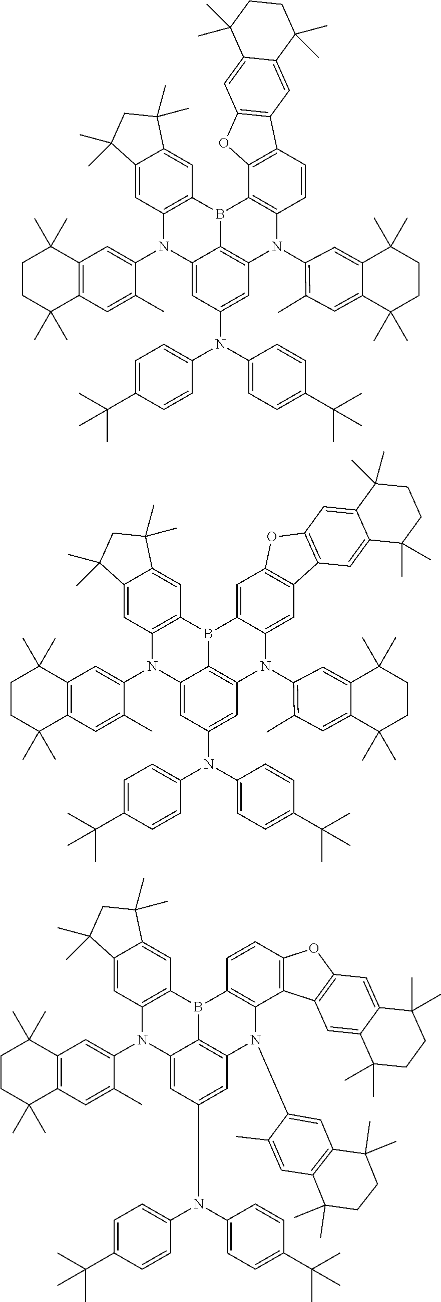

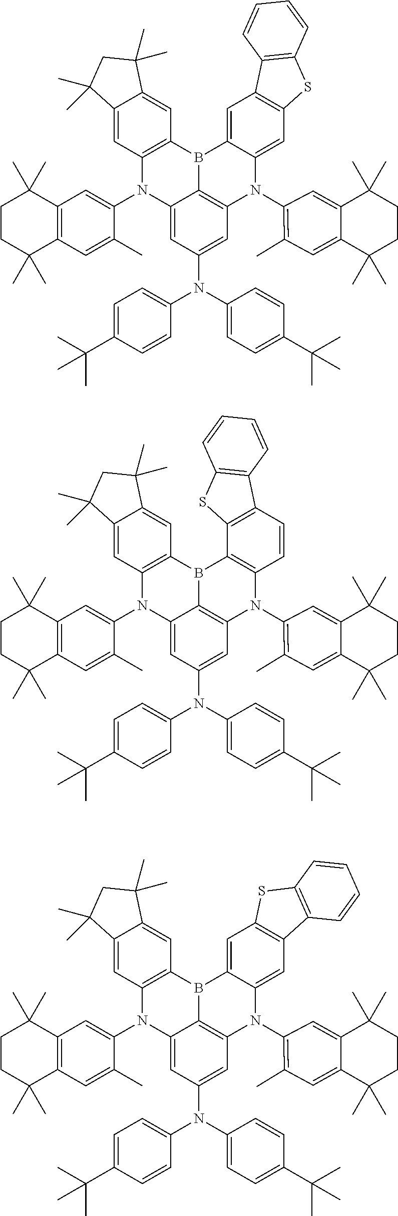 [SMILES: Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)sc1ccccc16)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1cc5c(cc1C)C(C)(C)CCC5(C)C)c1ccc5c(sc6ccccc65)c13)C(C)(C)CC4(C)C)C(C)(C)CCC2(C)C ; Cc1cc2c(cc1N1c3cc4c(cc3B3c5cc6sc7ccccc7c6cc5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C]

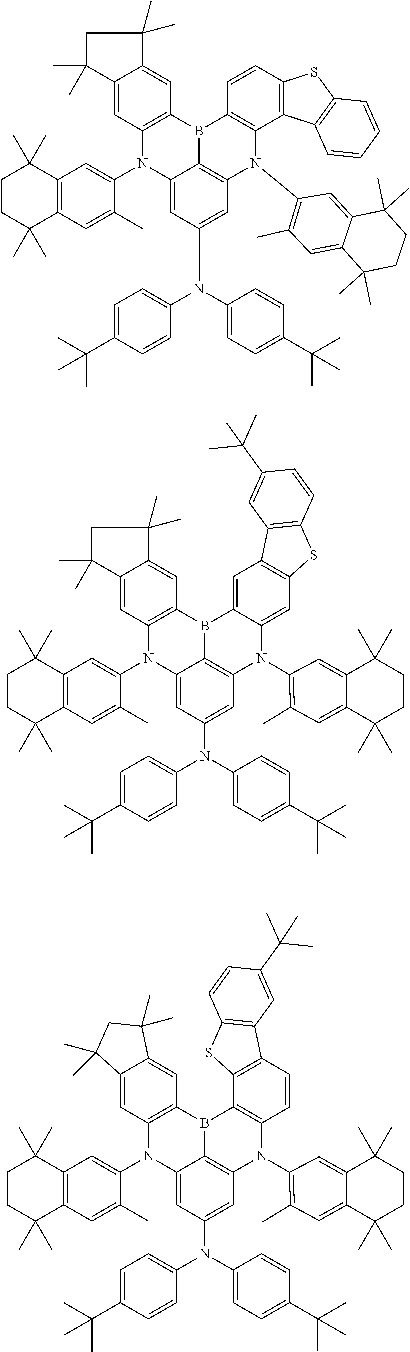 [SMILES: Cc1cc2c(cc1N1c3cc4c(cc3B3c5ccc6sc7ccccc7c6c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)sc1ccc(C(C)(C)C)cc16)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1cc5c(cc1C)C(C)(C)CCC5(C)C)c1ccc5c(sc6ccc(C(C)(C)C)cc65)c13)C(C)(C)CC4(C)C)C(C)(C)CCC2(C)C]

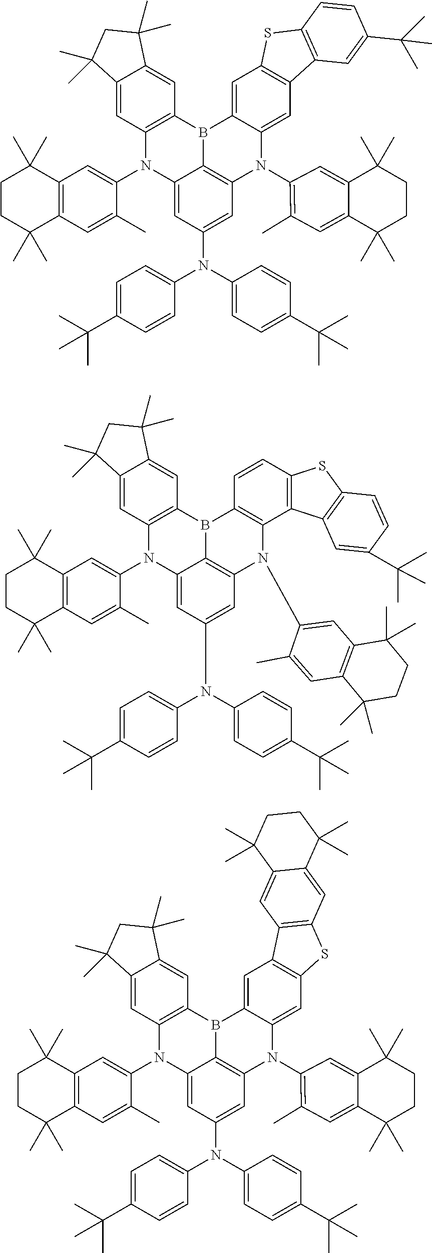

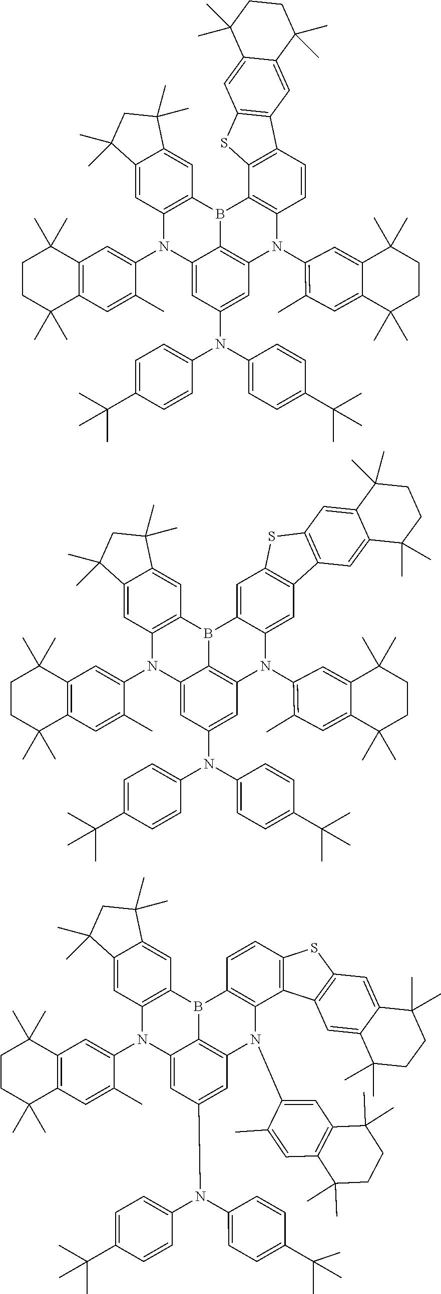

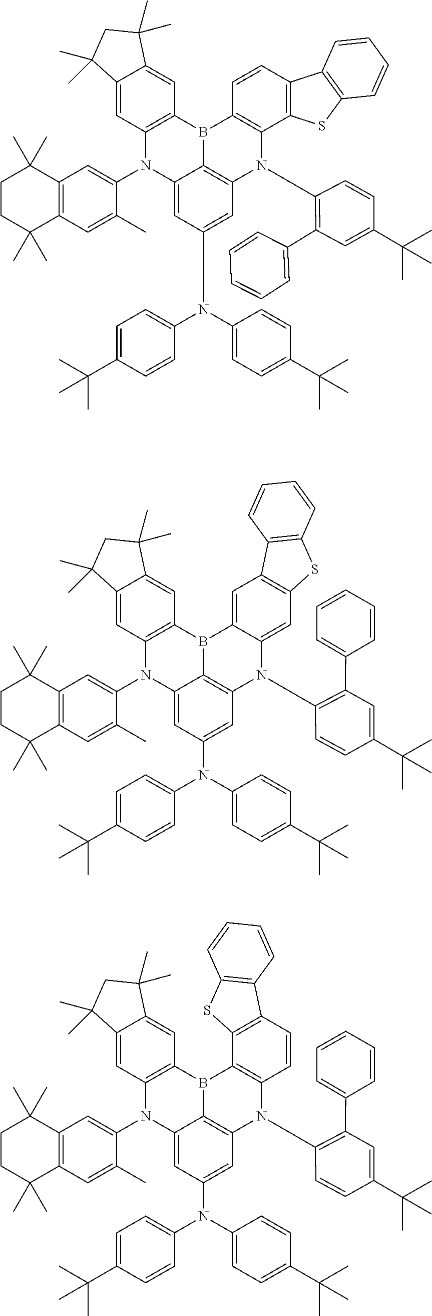 [SMILES: Cc1cc2c(cc1N1c3cc4c(cc3B3c5ccc6c(sc7ccccc76)c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)sc1ccccc16)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccc(C(C)(C)C)cc1-c1ccccc1)c1ccc5c(sc6ccccc65)c13)C(C)(C)CC4(C)C)C(C)(C)CCC2(C)C]

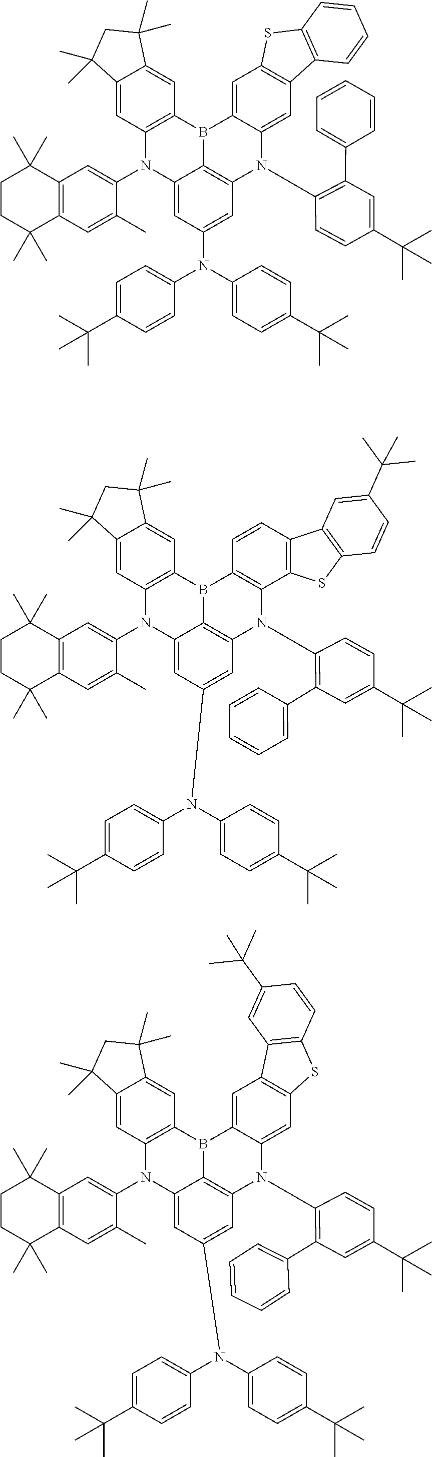 [SMILES: Cc1cc2c(cc1N1c3cc4c(cc3B3c5cc6sc7ccccc7c6cc5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)sc1ccc(C(C)(C)C)cc16)C(C)(C)CC4(C)C)C(C)(C)CCC2(C)C]

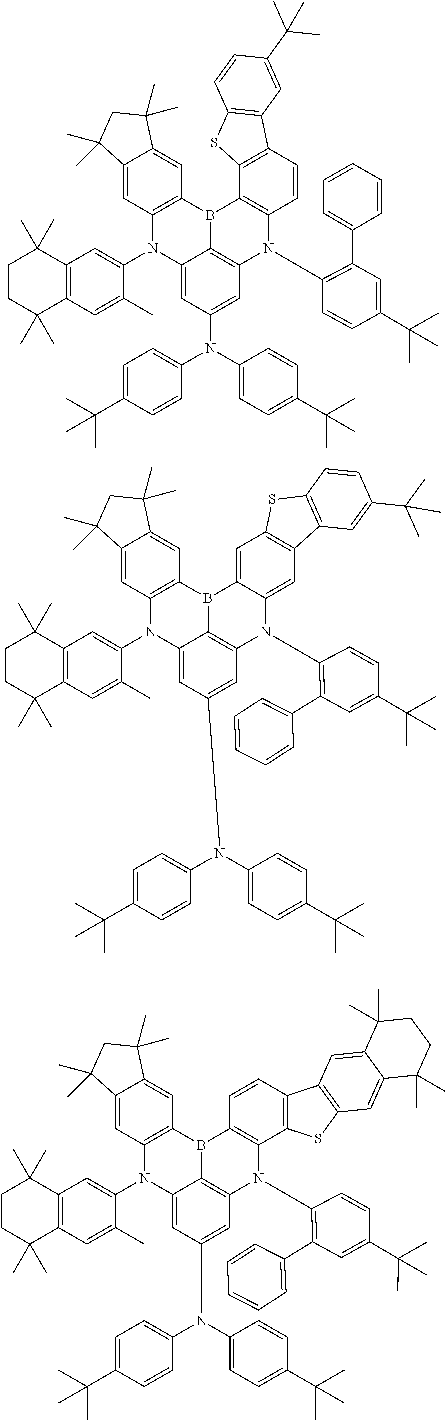

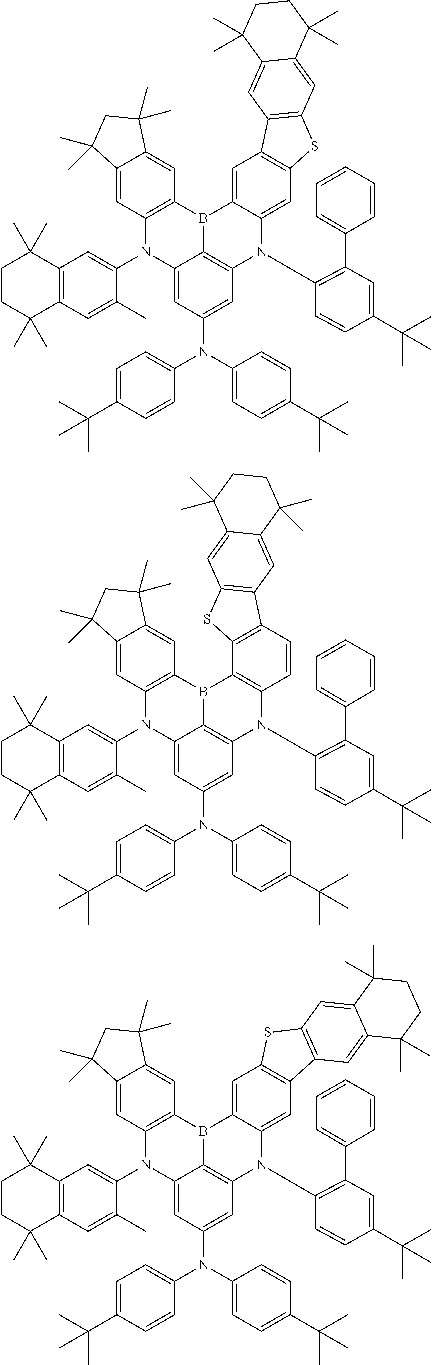

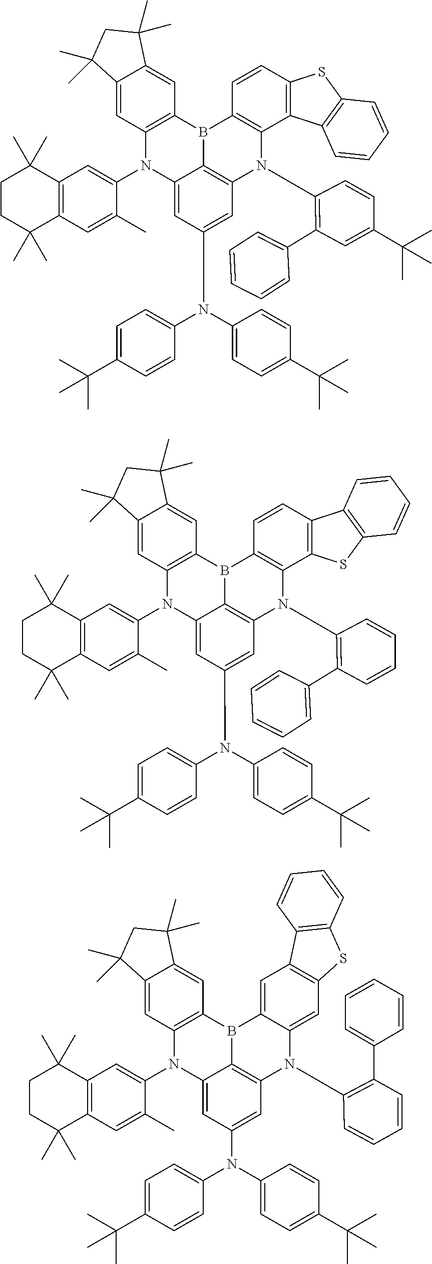

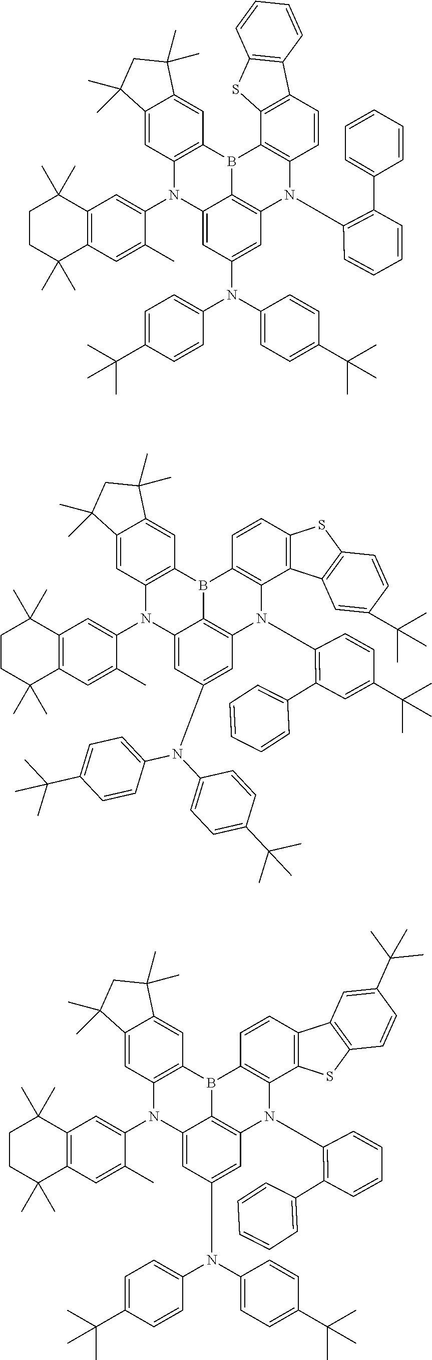 [SMILES: Cc1cc2c(cc1N1c3cc4c(cc3B3c5c1cc(N(c1ccc(C(C)(C)C)cc1)c1ccc(C(C)(C)C)cc1)cc5N(c1ccccc1-c1ccccc1)c1ccc5c(sc6ccccc65)c13)C(C)(C)CC4(C)C)C(C)(C)CCC2(C)C ; Cc1cc2c(cc1N1c3cc4c(cc3B3c5ccc6sc7ccc(C(C)(C)C)cc7c6c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C ; Cc1cc2c(cc1N1c3cc4c(cc3B3c5ccc6c(sc7ccc(C(C)(C)C)cc76)c5N(c5ccccc5-c5ccccc5)c5cc(N(c6ccc(C(C)(C)C)cc6)c6ccc(C(C)(C)C)cc6)cc1c53)C(C)(C)CC4(C)C)C(C)(C)CCC2(C)C]

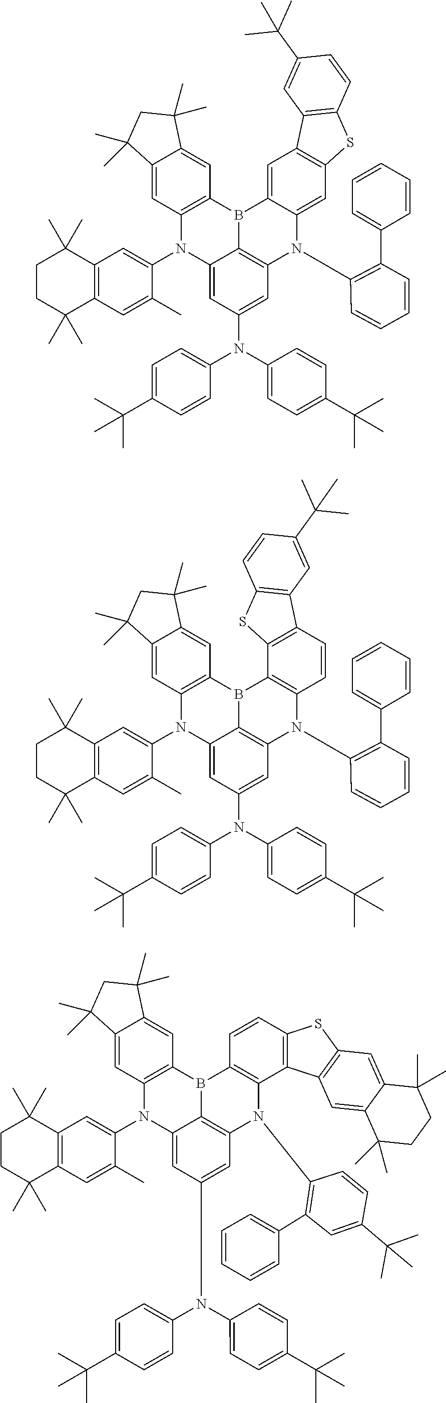

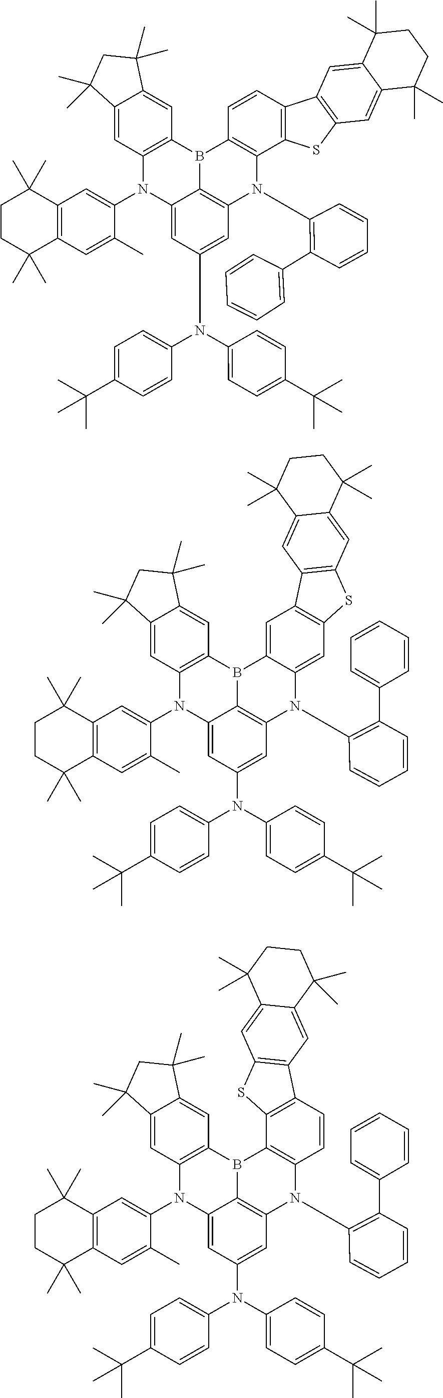

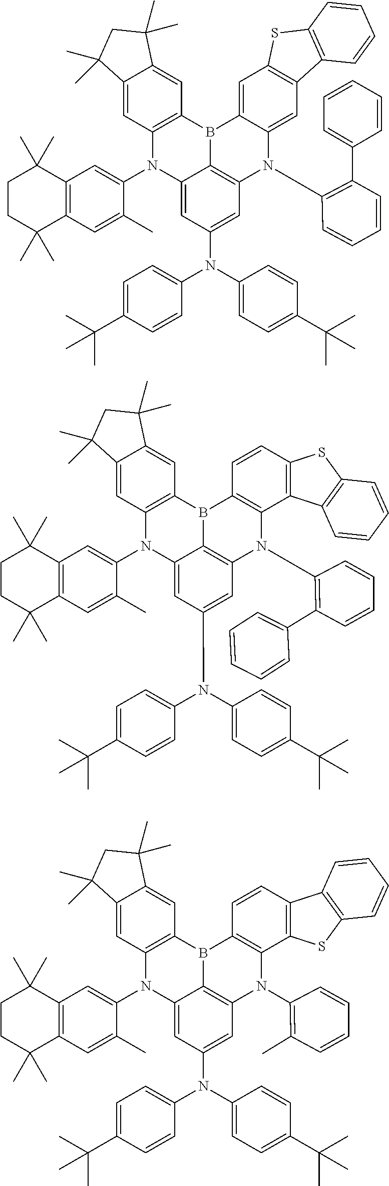

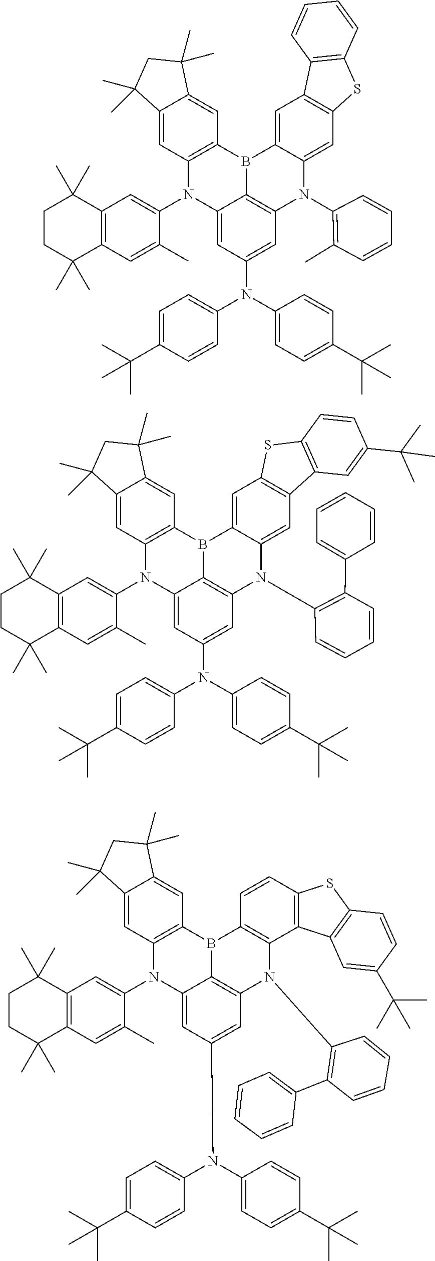

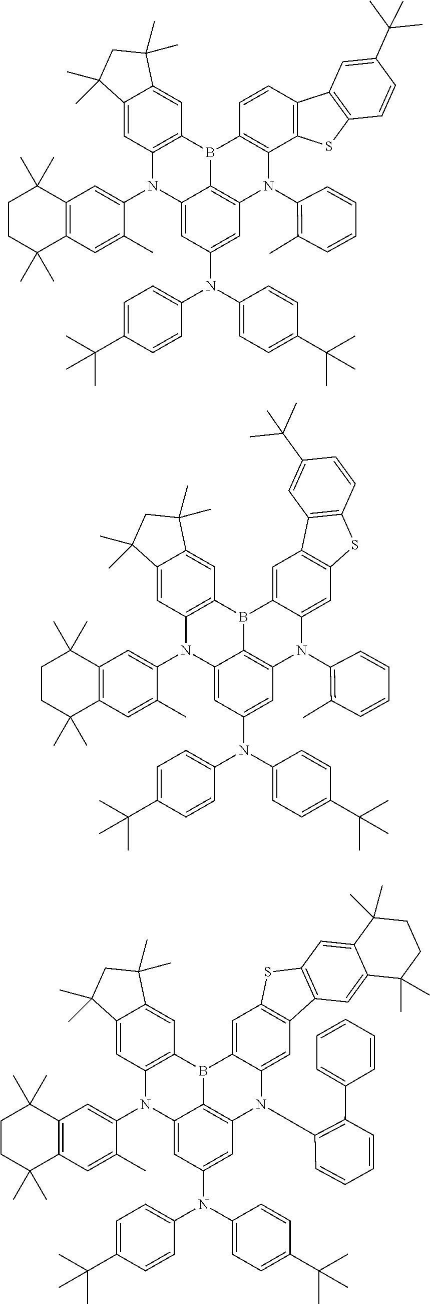

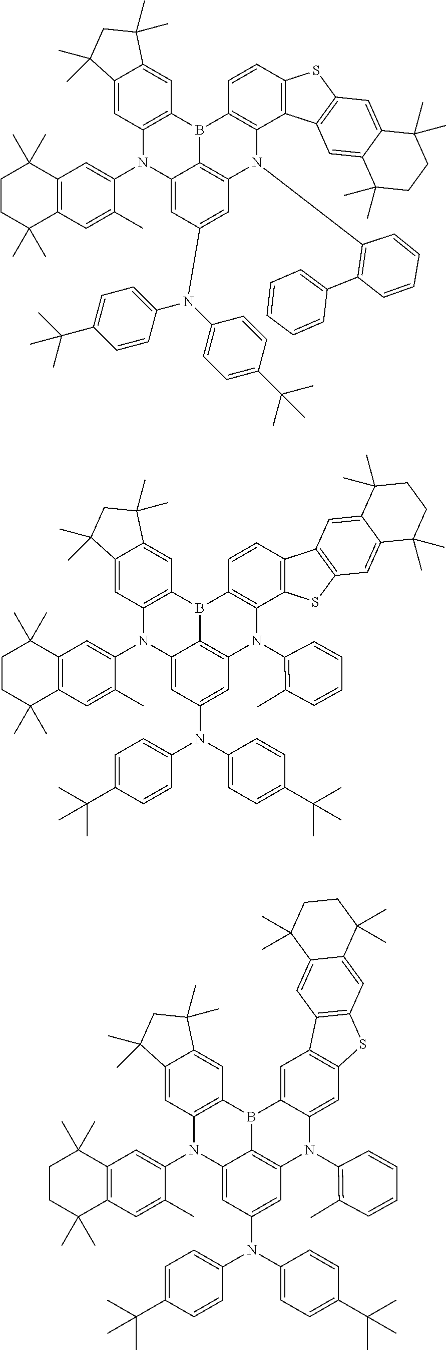 [SMILES: Cc1cc2c(cc1N1c3cc4c(cc3B3c5ccc6sc7cc8c(cc7c6c5N(c5ccccc5-c5ccccc5)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5ccccc5C)c5cc(N(c6ccc(C(C)(C)C)cc6)c6ccc(C(C)(C)C)cc6)cc1c53)C(C)(C)CC4(C)C)C(C)(C)CCC2(C)C ; Cc1ccccc1N1c2cc3sc4cc5c(cc4c3cc2B2c3cc4c(cc3N(c3cc6c(cc3C)C(C)(C)CCC6(C)C)c3cc(N(c6ccc(C(C)(C)C)cc6)c6ccc(C(C)(C)C)cc6)cc1c32)C(C)(C)CC4(C)C)C(C)(C)CCC5(C)C]

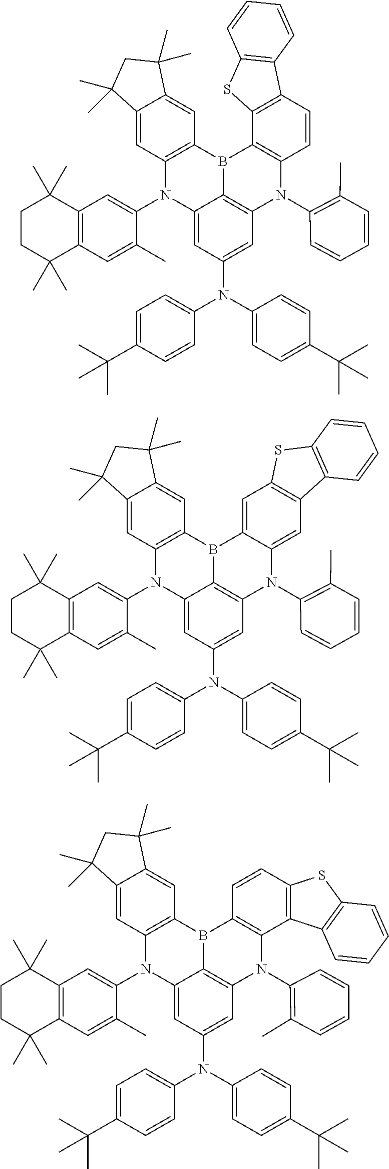

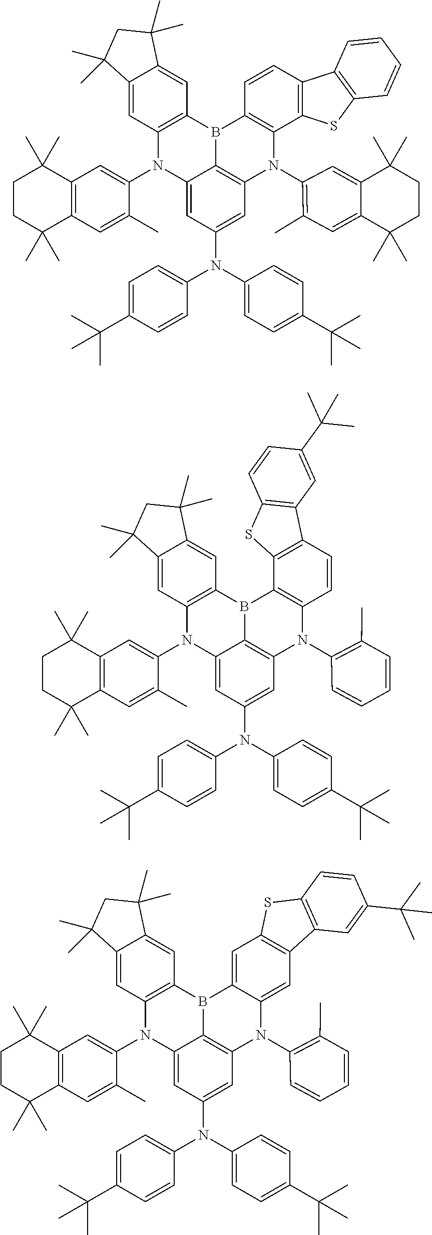

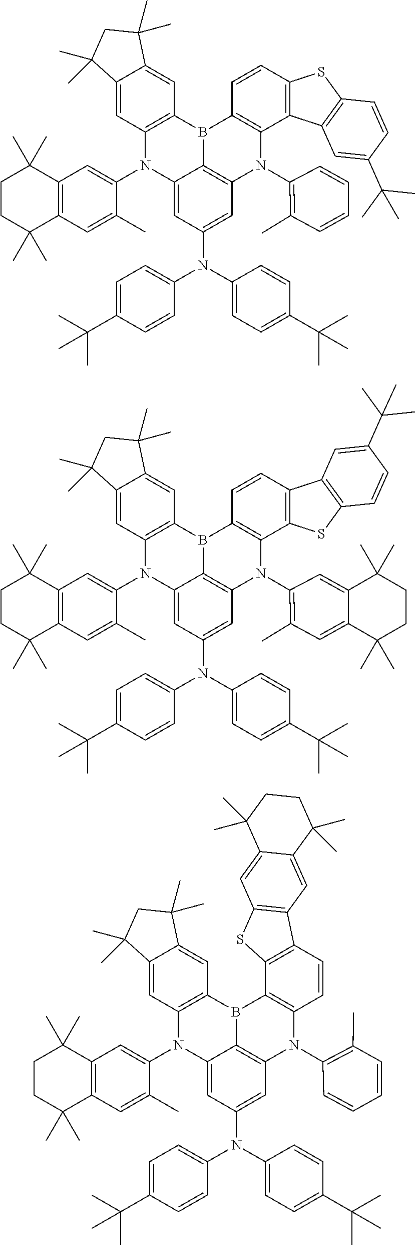

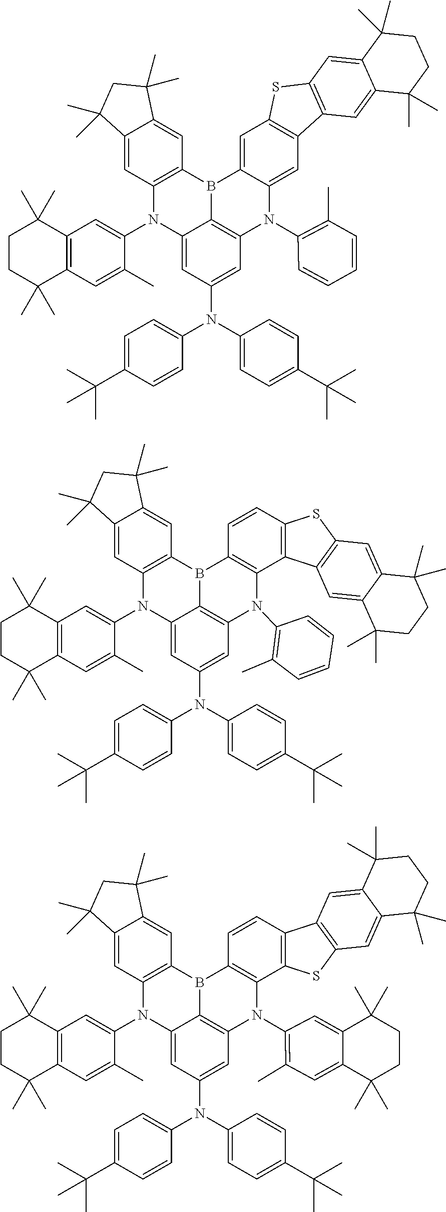 [SMILES: Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)CC5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(N(c6ccc(C(C)(C)C)cc6)c6ccc(C(C)(C)C)cc6)cc1c53)C(C)(C)CCC8(C)C)C(C)(C)CC4(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)CC4(C)C)C(C)(C)CCC2(C)C]

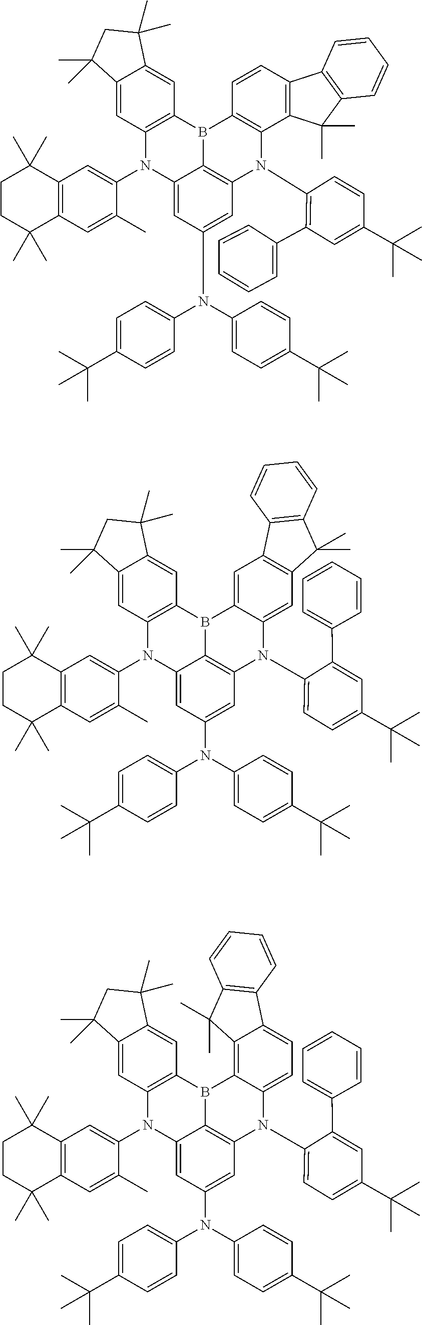

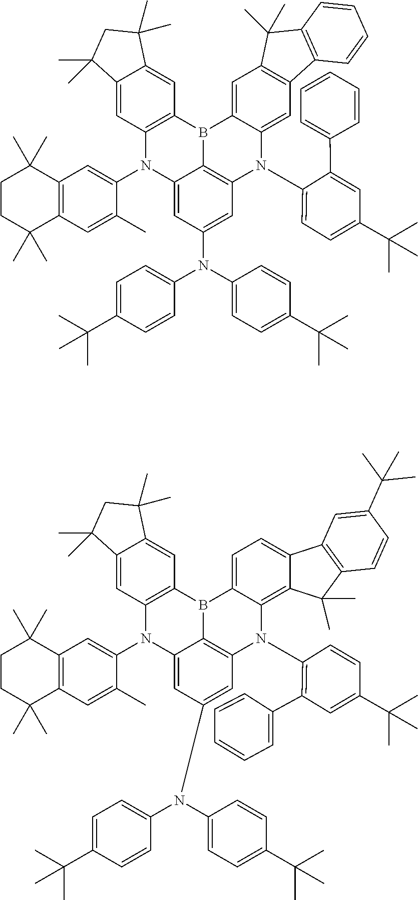 [SMILES: Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)-c1ccccc1C6(C)C)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(N(c7ccc(C(C)(C)C)cc7)c7ccc(C(C)(C)C)cc7)cc1c53)C(C)(C)c1ccc(C(C)(C)C)cc1-6)C(C)(C)CC4(C)C)C(C)(C)CCC2(C)C]

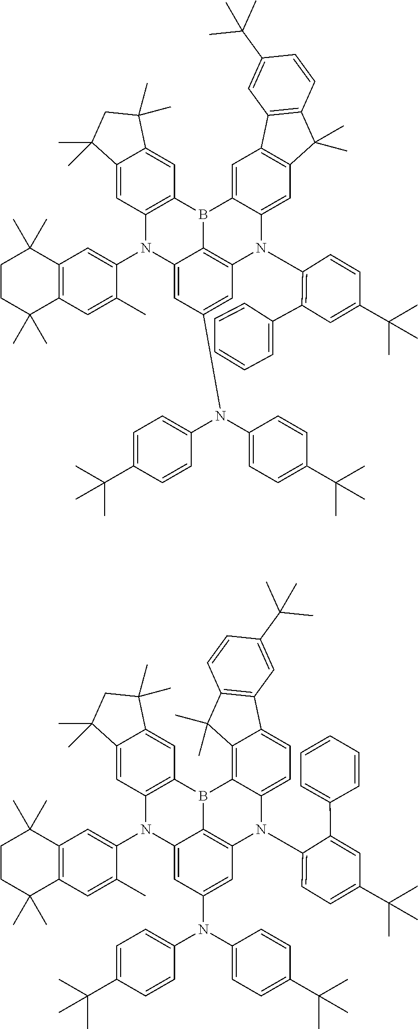 [SMILES: Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)C(C)(C)c1ccc(C(C)(C)C)cc1-6)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccc(C(C)(C)C)cc1-c1ccccc1)c1ccc5c(c13)C(C)(C)c1ccc(C(C)(C)C)cc1-5)C(C)(C)CC4(C)C)C(C)(C)CCC2(C)C]

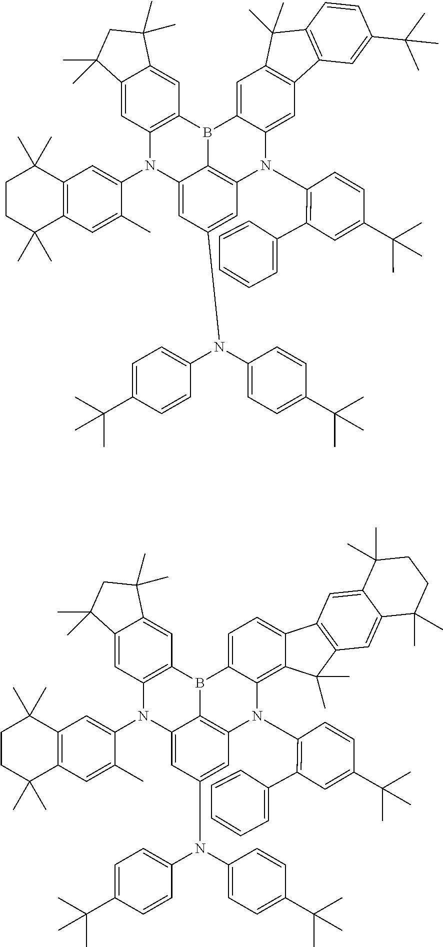 [SMILES: Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)-c1cc(C(C)(C)C)ccc1C6(C)C)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(N(c7ccc(C(C)(C)C)cc7)c7ccc(C(C)(C)C)cc7)cc1c53)C(C)(C)c1cc3c(cc1-6)C(C)(C)CCC3(C)C)C(C)(C)CC4(C)C)C(C)(C)CCC2(C)C]

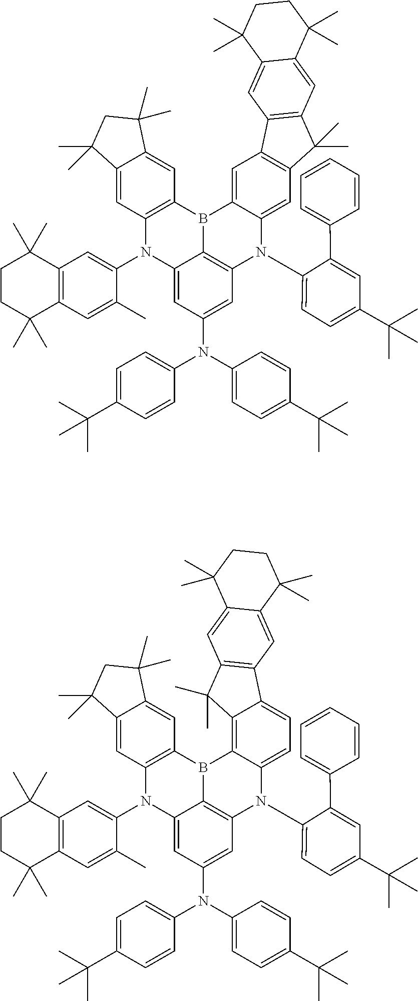 [SMILES: Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccc(C(C)(C)C)cc1-c1ccccc1)c1ccc5c(c13)C(C)(C)c1cc3c(cc1-5)C(C)(C)CCC3(C)C)C(C)(C)CC4(C)C)C(C)(C)CCC2(C)C]

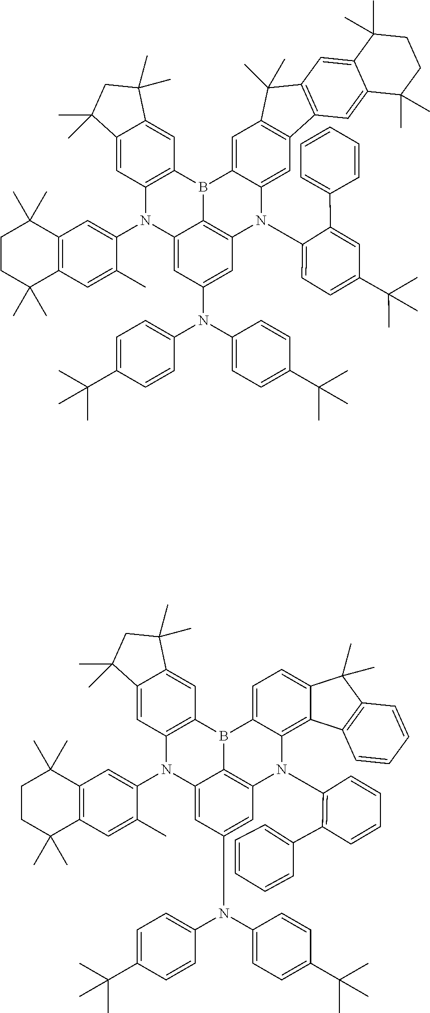 [SMILES: Cc1cc2c(cc1N1c3cc4c(cc3B3c5cc6c(cc5N(c5ccc(C(C)(C)C)cc5-c5ccccc5)c5cc(N(c7ccc(C(C)(C)C)cc7)c7ccc(C(C)(C)C)cc7)cc1c53)-c1cc3c(cc1C6(C)C)C(C)(C)CCC3(C)C)C(C)(C)CC4(C)C)C(C)(C)CCC2(C)C ; Cc1cc2c(cc1N1c3cc4c(cc3B3c5ccc6c(c5N(c5ccccc5-c5ccccc5)c5cc(N(c7ccc(C(C)(C)C)cc7)c7ccc(C(C)(C)C)cc7)cc1c53)-c1ccccc1C6(C)C)C(C)(C)CC4(C)C)C(C)(C)CCC2(C)C]

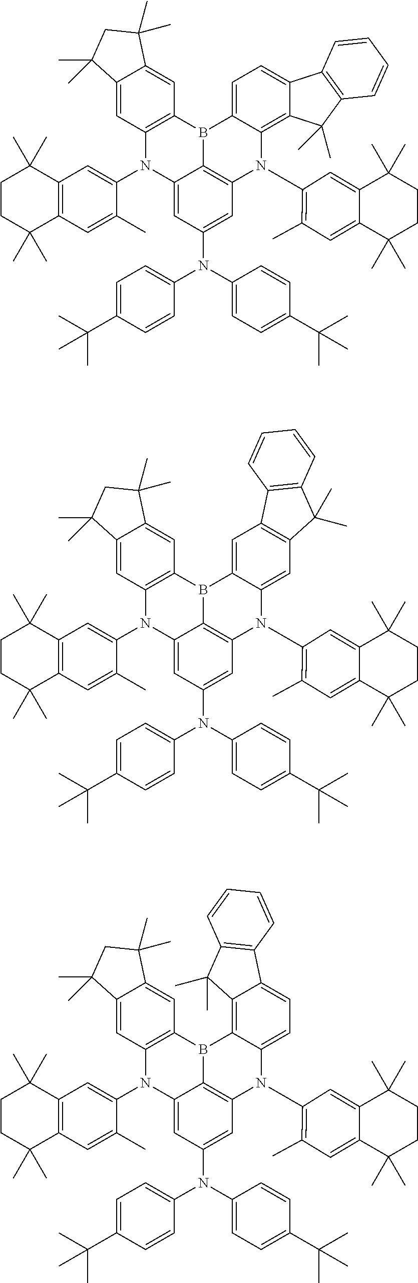

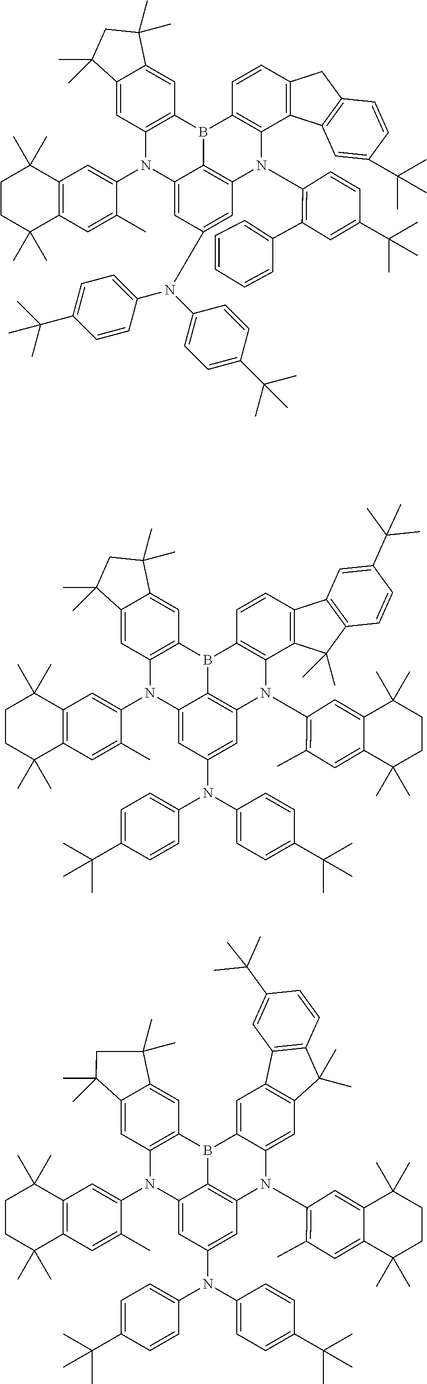

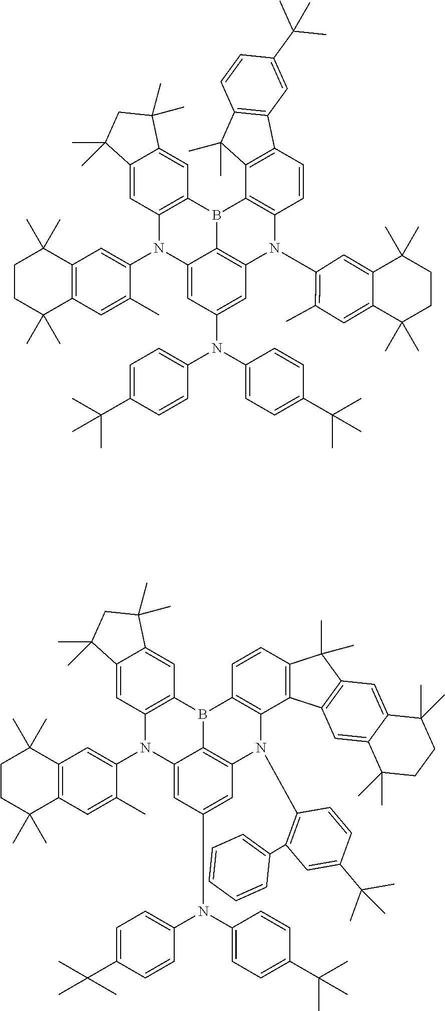 [SMILES: Cc1cc2c(cc1N1c3cc4c(cc3B3c5c1cc(N(c1ccc(C(C)(C)C)cc1)c1ccc(C(C)(C)C)cc1)cc5N(c1cc5c(cc1C)C(C)(C)CCC5(C)C)c1ccc5c(c13)C(C)(C)c1ccc(C(C)(C)C)cc1-5)C(C)(C)CC4(C)C)C(C)(C)CCC2(C)C ; Cc1cc2c(cc1N1c3cc4c(cc3B3c5ccc6c(c5N(c5ccc(C(C)(C)C)cc5-c5ccccc5)c5cc(N(c7ccc(C(C)(C)C)cc7)c7ccc(C(C)(C)C)cc7)cc1c53)-c1cc3c(cc1C6(C)C)C(C)(C)CCC3(C)C)C(C)(C)CC4(C)C)C(C)(C)CCC2(C)C]

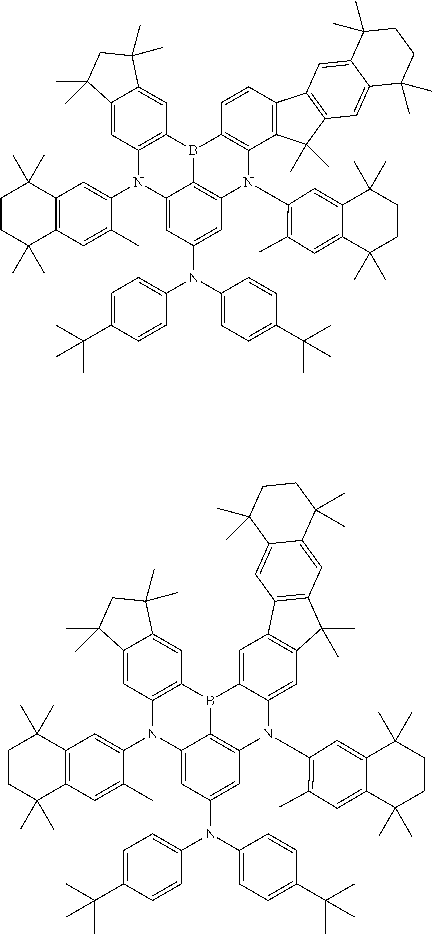 [SMILES: Cc1cc2c(cc1N1c3cc4c(cc3B3c5ccc6c(c5N(c5cc7c(cc5C)C(C)(C)CCC7(C)C)c5cc(N(c7ccc(C(C)(C)C)cc7)c7ccc(C(C)(C)C)cc7)cc1c53)C(C)(C)c1cc3c(cc1-6)C(C)(C)CCC3(C)C)C(C)(C)CC4(C)C)C(C)(C)CCC2(C)C ; Cc1cc2c(cc1N1c3cc4c(cc3B3c5cc6c(cc5N(c5cc7c(cc5C)C(C)(C)CCC7(C)C)c5cc(N(c7ccc(C(C)(C)C)cc7)c7ccc(C(C)(C)C)cc7)cc1c53)C(C)(C)c1cc3c(cc1-6)C(C)(C)CCC3(C)C)C(C)(C)CC4(C)C)C(C)(C)CCC2(C)C]

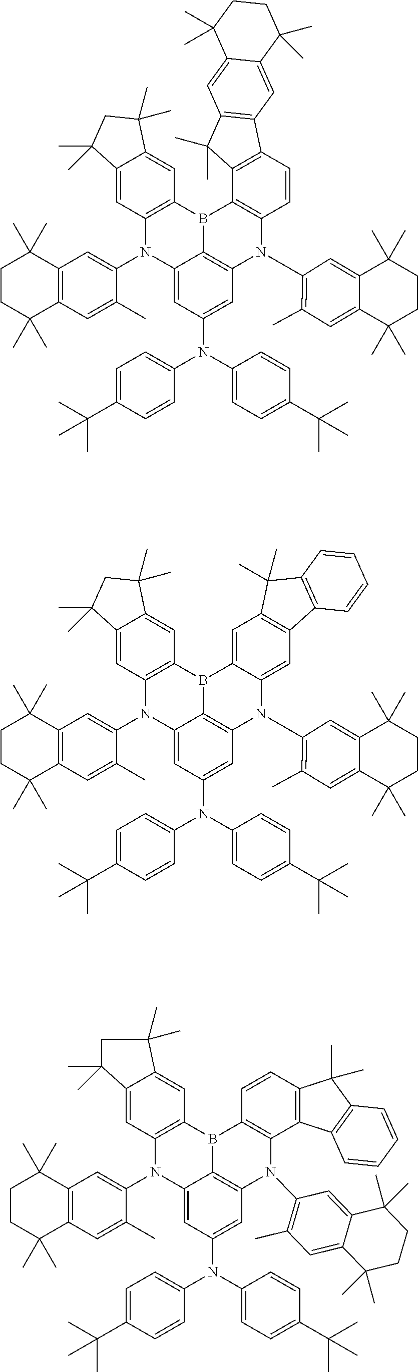

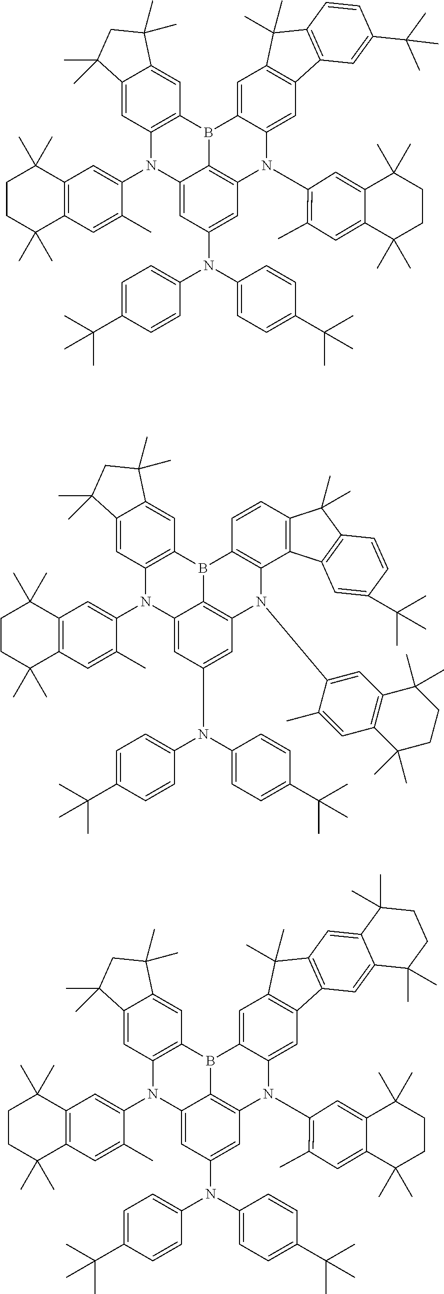

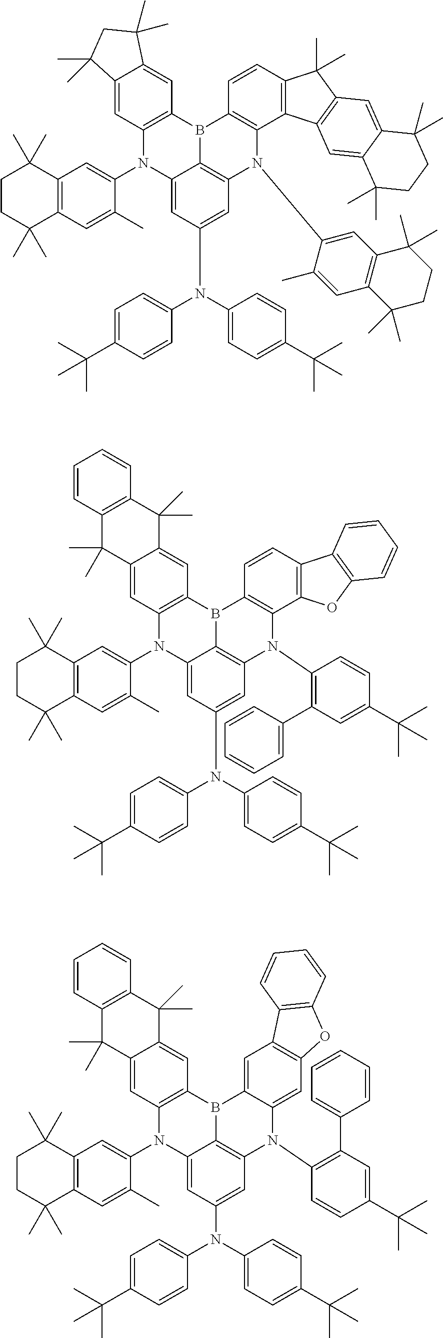

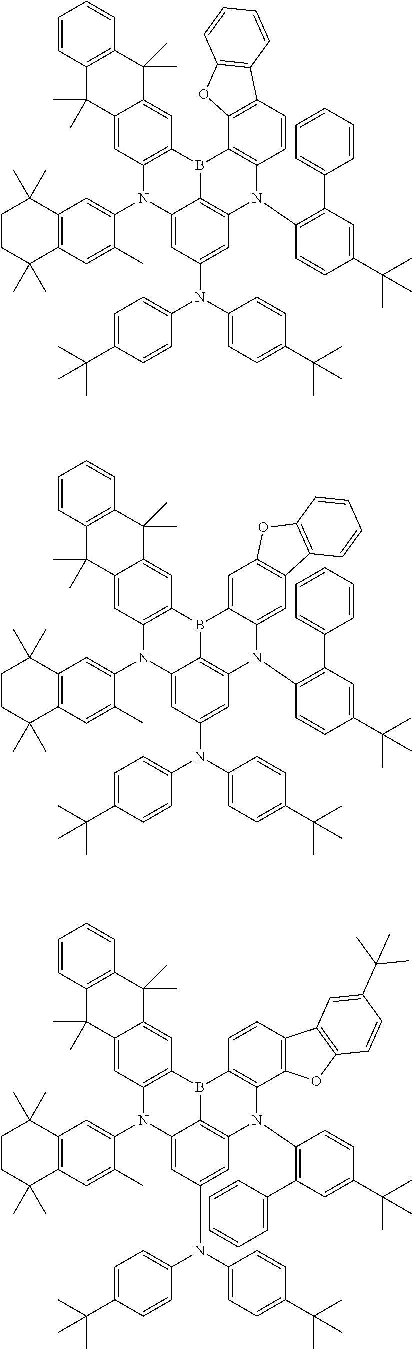

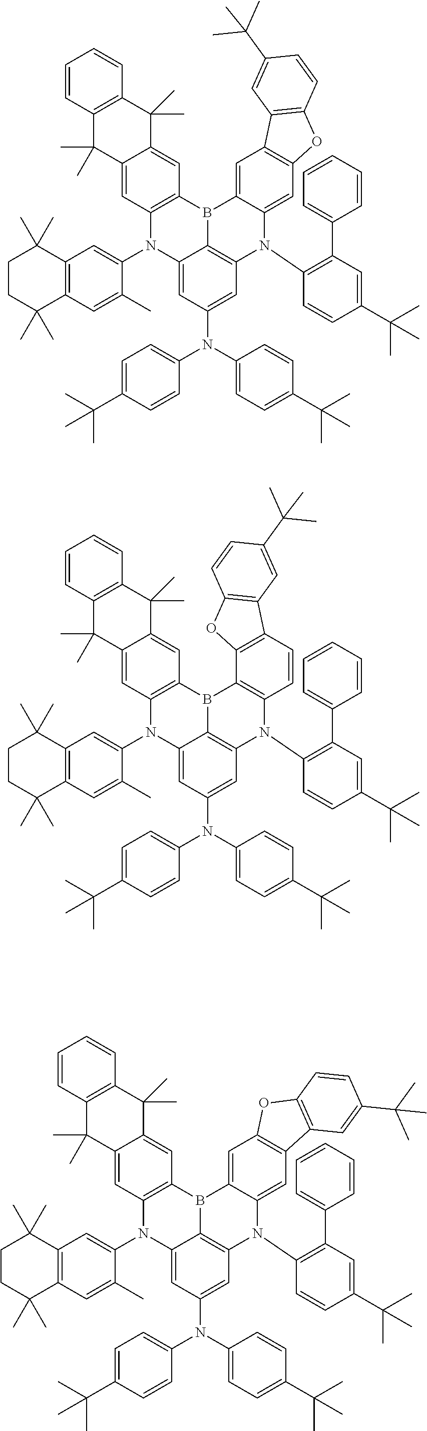

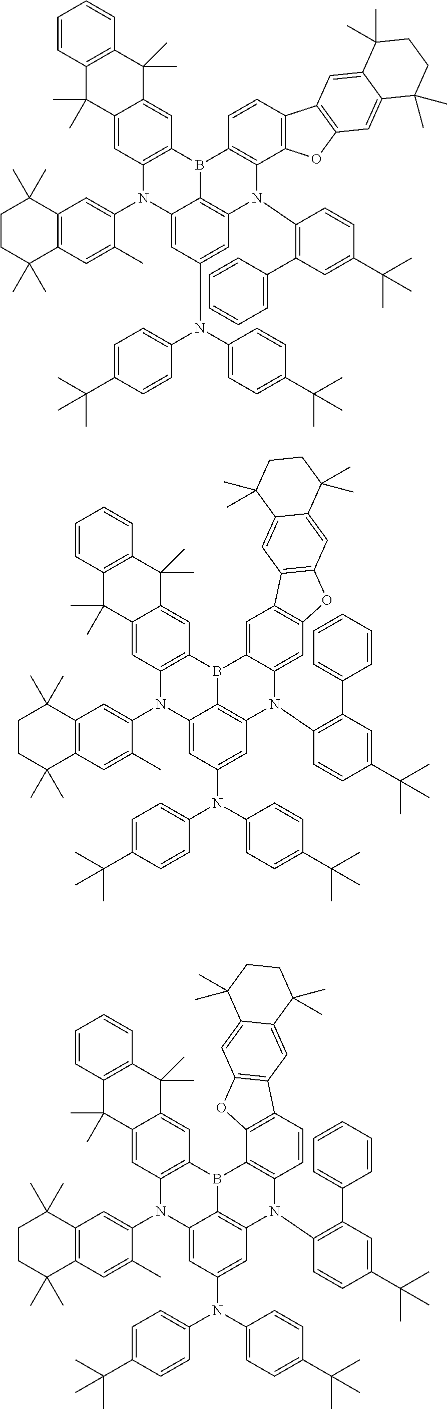

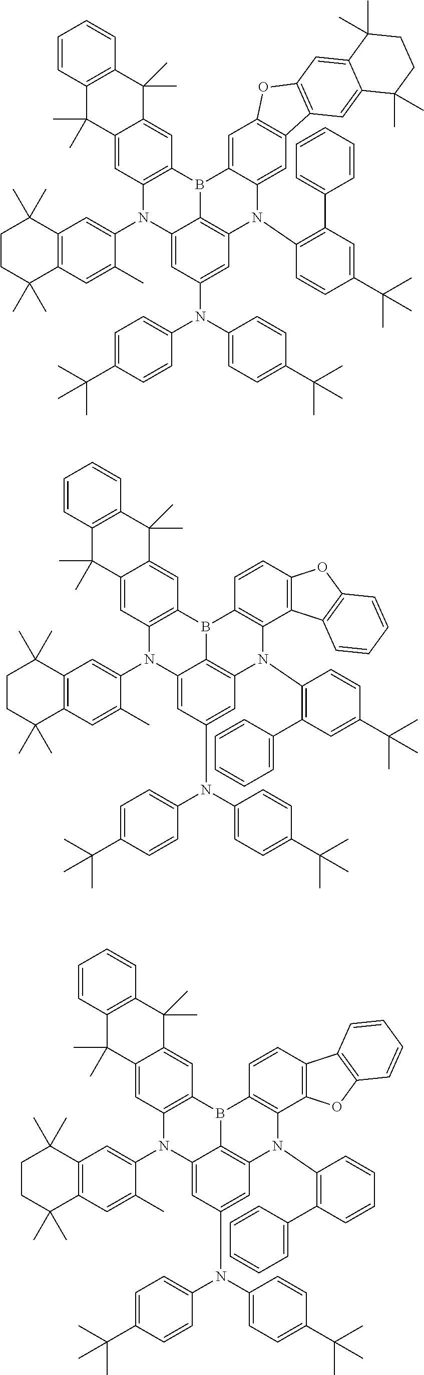

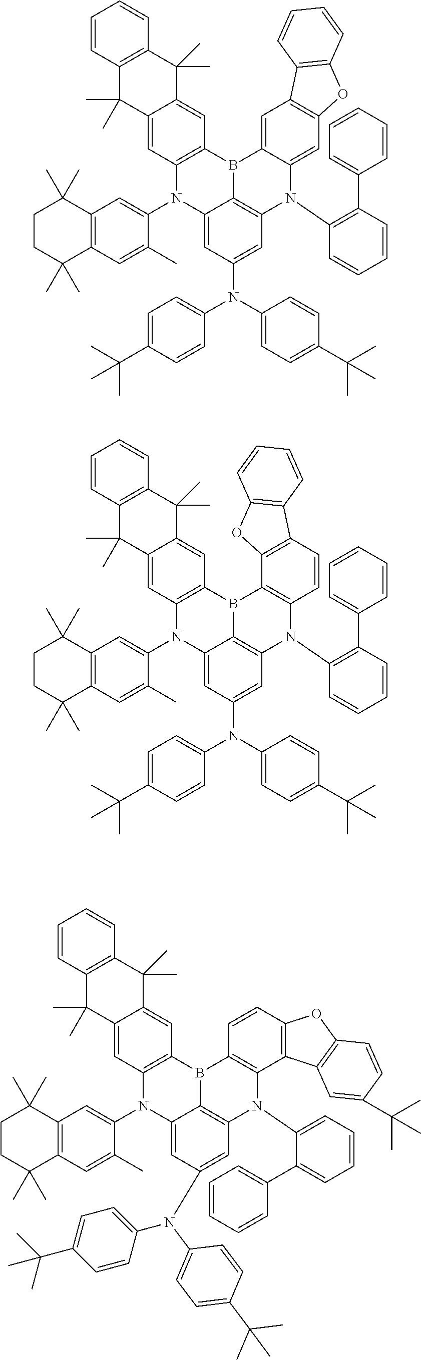

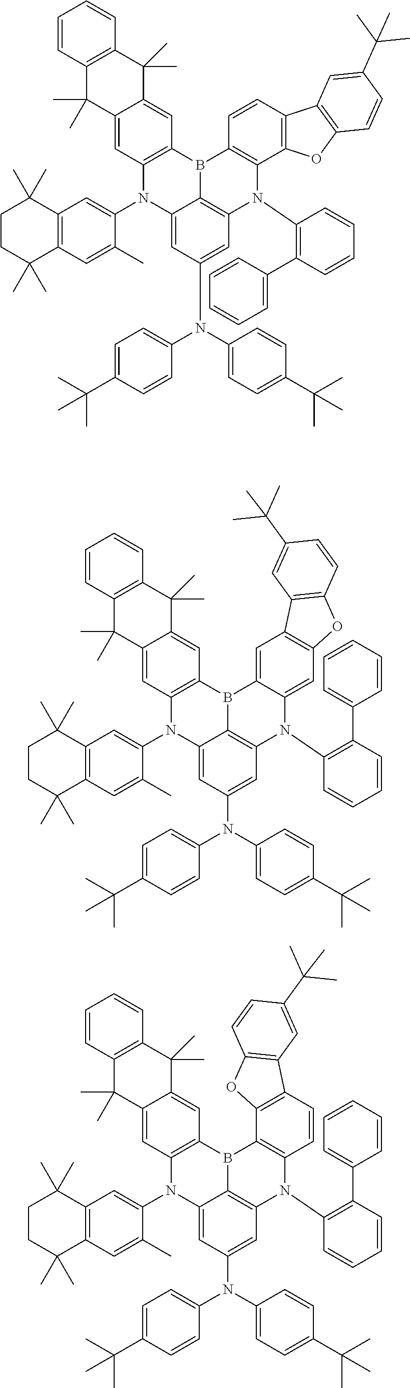

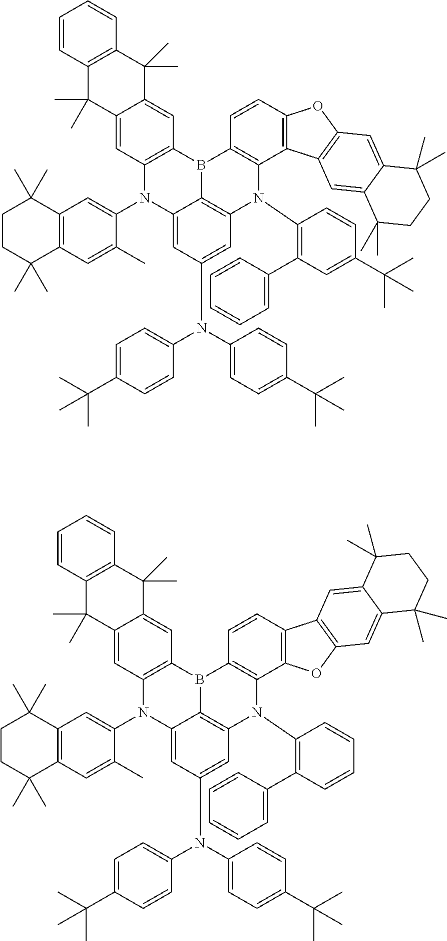 [SMILES: Cc1cc2c(cc1N1c3cc4c(cc3B3c5ccc6oc7cc8c(cc7c6c5N(c5ccc(C(C)(C)C)cc5-c5ccccc5)c5cc(N(c6ccc(C(C)(C)C)cc6)c6ccc(C(C)(C)C)cc6)cc1c53)C(C)(C)CCC8(C)C)C(C)(C)c1ccccc1C4(C)C)C(C)(C)CCC2(C)C ; Cc1cc2c(cc1N1c3cc4c(cc3B3c5ccc6c(oc7cc8c(cc76)C(C)(C)CCC8(C)C)c5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

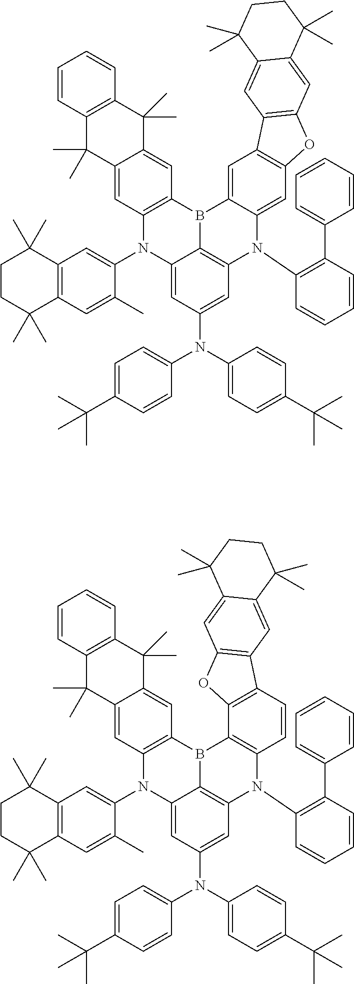 [SMILES: Cc1cc2c(cc1N1c3cc4c(cc3B3c5cc6c(cc5N(c5ccccc5-c5ccccc5)c5cc(N(c7ccc(C(C)(C)C)cc7)c7ccc(C(C)(C)C)cc7)cc1c53)oc1cc3c(cc16)C(C)(C)CCC3(C)C)C(C)(C)c1ccccc1C4(C)C)C(C)(C)CCC2(C)C ; Cc1cc2c(cc1N1c3cc4c(cc3B3c5c1cc(N(c1ccc(C(C)(C)C)cc1)c1ccc(C(C)(C)C)cc1)cc5N(c1ccccc1-c1ccccc1)c1ccc5c(oc6cc7c(cc65)C(C)(C)CCC7(C)C)c13)C(C)(C)c1ccccc1C4(C)C)C(C)(C)CCC2(C)C]

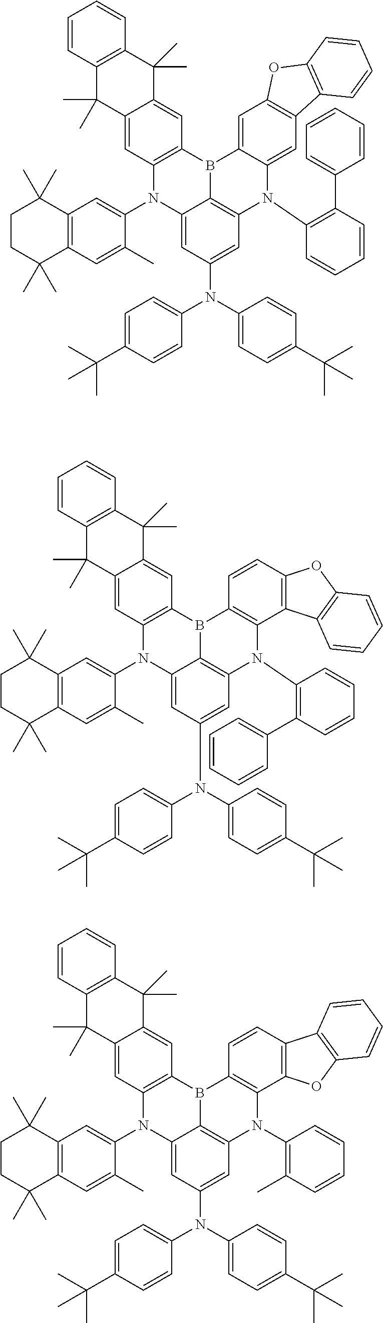

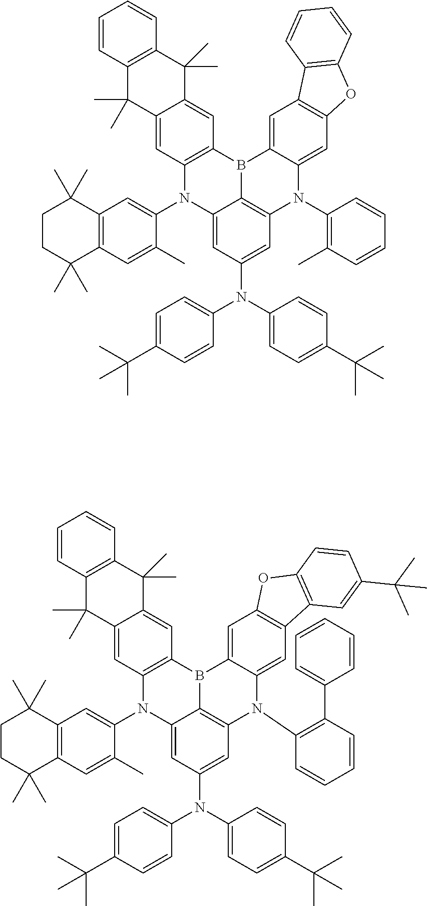 [SMILES: Cc1ccccc1N1c2cc3oc4ccccc4c3cc2B2c3cc4c(cc3N(c3cc5c(cc3C)C(C)(C)CCC5(C)C)c3cc(N(c5ccc(C(C)(C)C)cc5)c5ccc(C(C)(C)C)cc5)cc1c32)C(C)(C)c1ccccc1C4(C)C ; Cc1cc2c(cc1N1c3cc4c(cc3B3c5cc6oc7ccc(C(C)(C)C)cc7c6cc5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

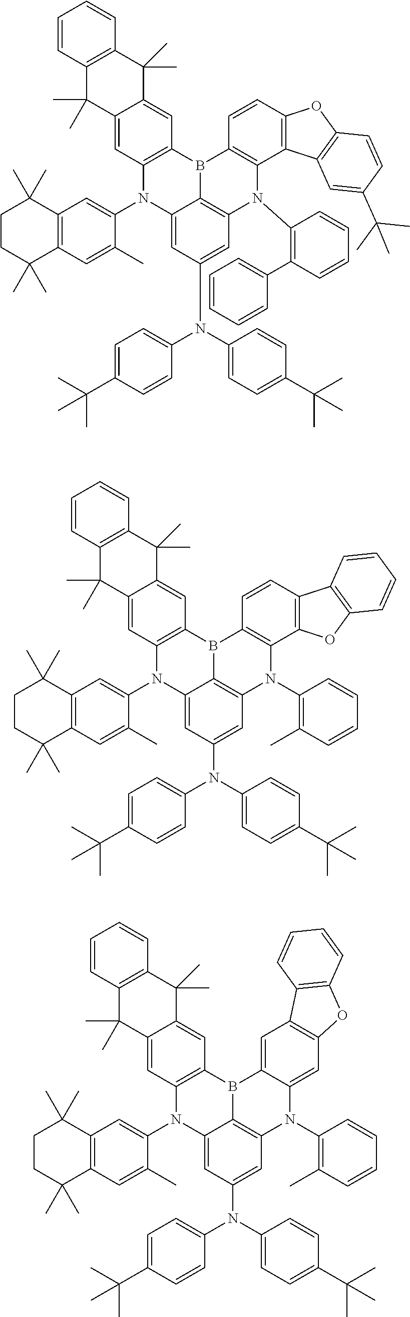 [SMILES: Cc1cc2c(cc1N1c3cc4c(cc3B3c5ccc6oc7ccc(C(C)(C)C)cc7c6c5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5ccccc5C)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1ccccc1N1c2cc3oc4ccccc4c3cc2B2c3cc4c(cc3N(c3cc5c(cc3C)C(C)(C)CCC5(C)C)c3cc(N(c5ccc(C(C)(C)C)cc5)c5ccc(C(C)(C)C)cc5)cc1c32)C(C)(C)c1ccccc1C4(C)C]

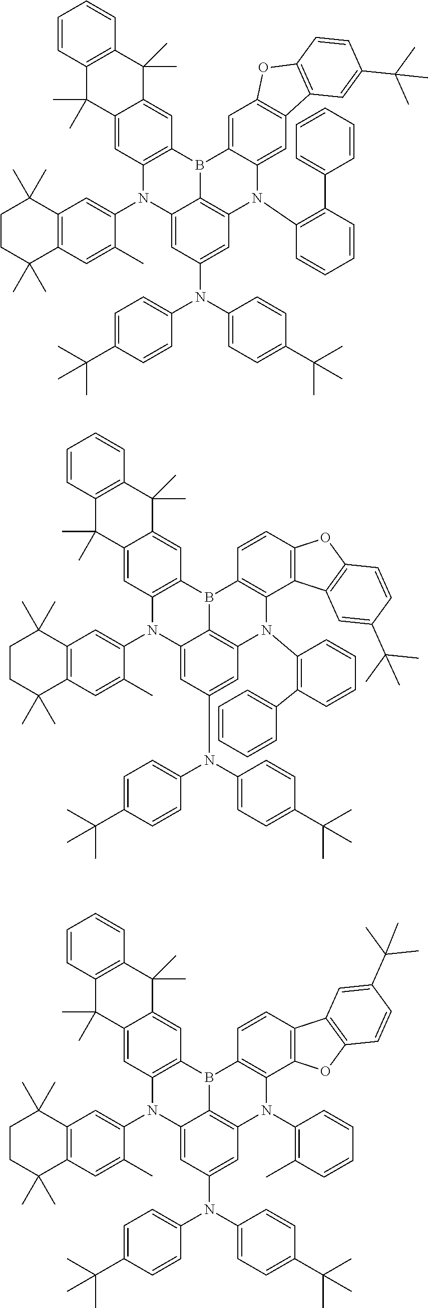

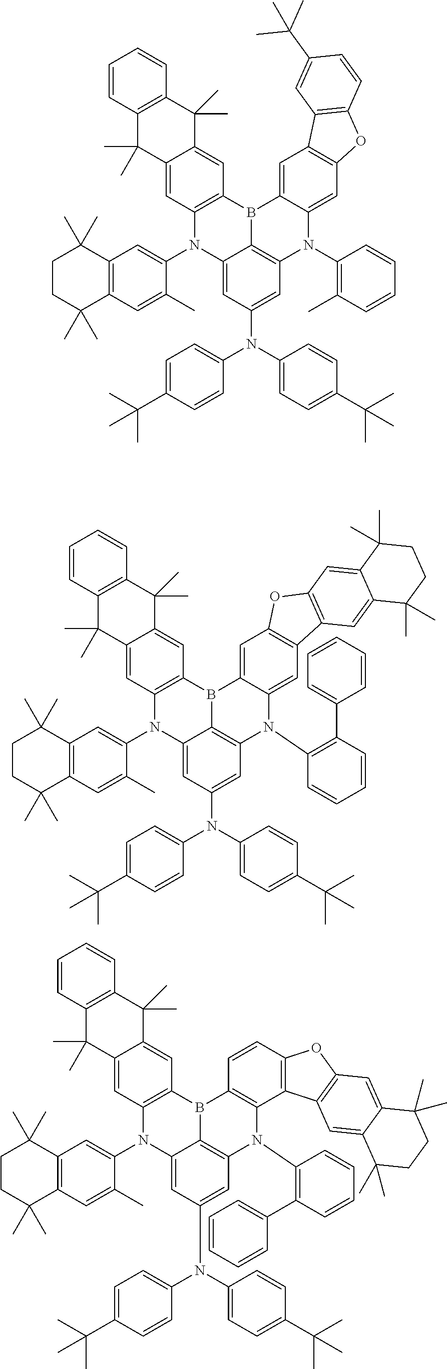

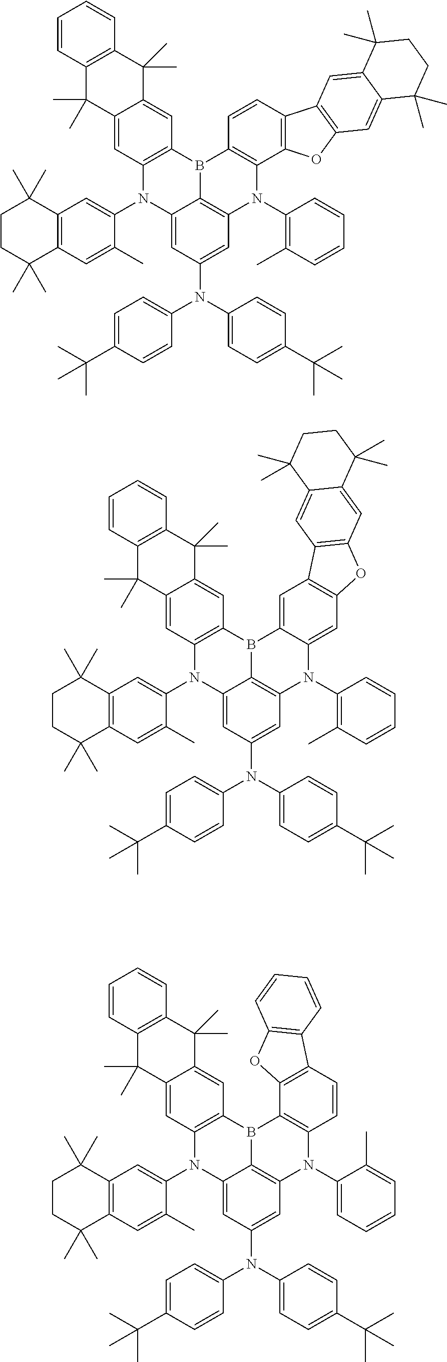

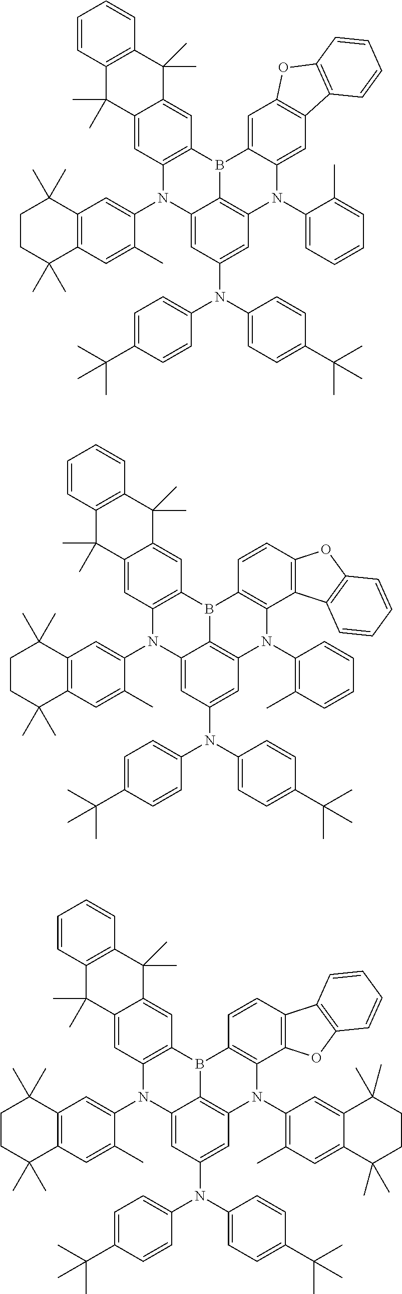 [SMILES: Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)c1ccccc1C5(C)C)oc1ccccc13 ; Cc1cc2c(cc1N1c3cc4c(cc3B3c5ccc6oc7ccccc7c6c5N(c5ccccc5C)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1cc2c(cc1N1c3cc4c(cc3B3c5ccc6c(oc7ccccc76)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

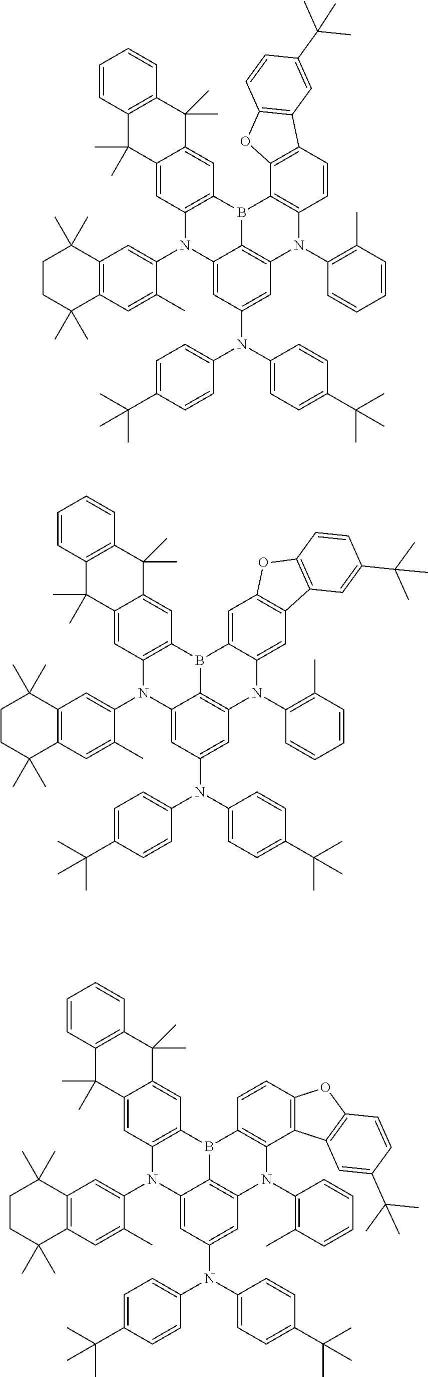 [SMILES: Cc1cc2c(cc1N1c3cc4c(cc3B3c5c1cc(N(c1ccc(C(C)(C)C)cc1)c1ccc(C(C)(C)C)cc1)cc5N(c1ccccc1C)c1ccc5c(oc6ccc(C(C)(C)C)cc65)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)c1ccccc1C5(C)C)oc1ccc(C(C)(C)C)cc13 ; Cc1cc2c(cc1N1c3cc4c(cc3B3c5ccc6oc7ccc(C(C)(C)C)cc7c6c5N(c5ccccc5C)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

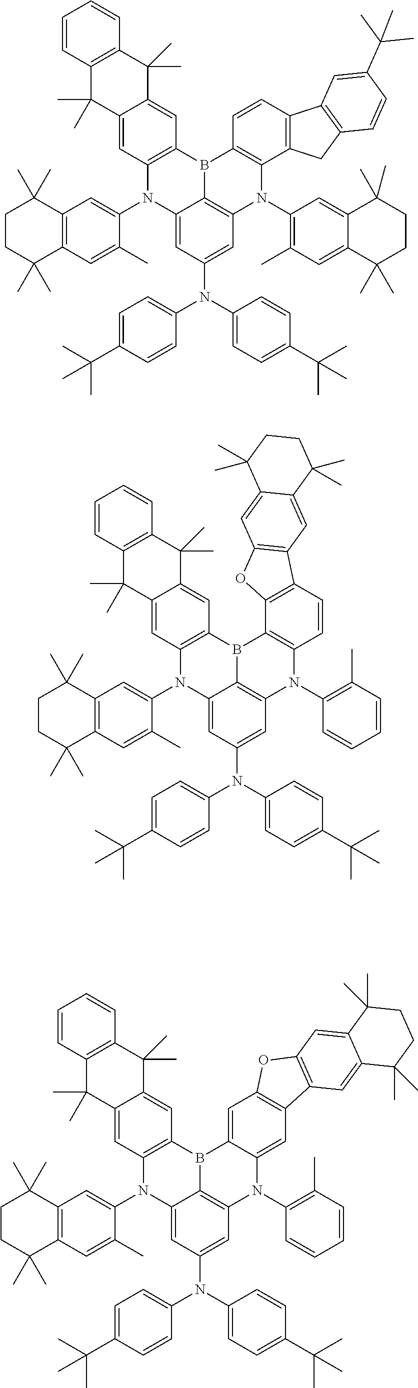

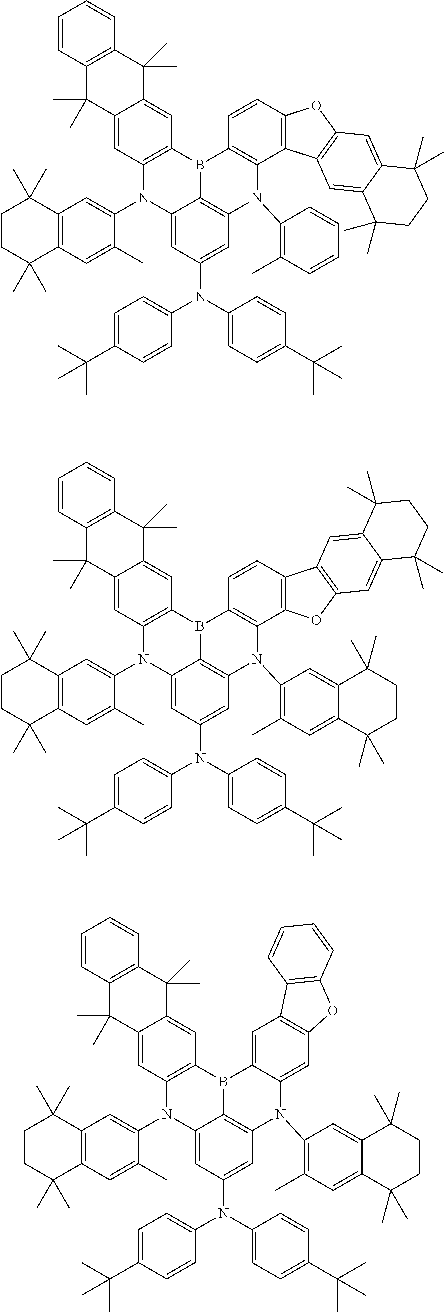

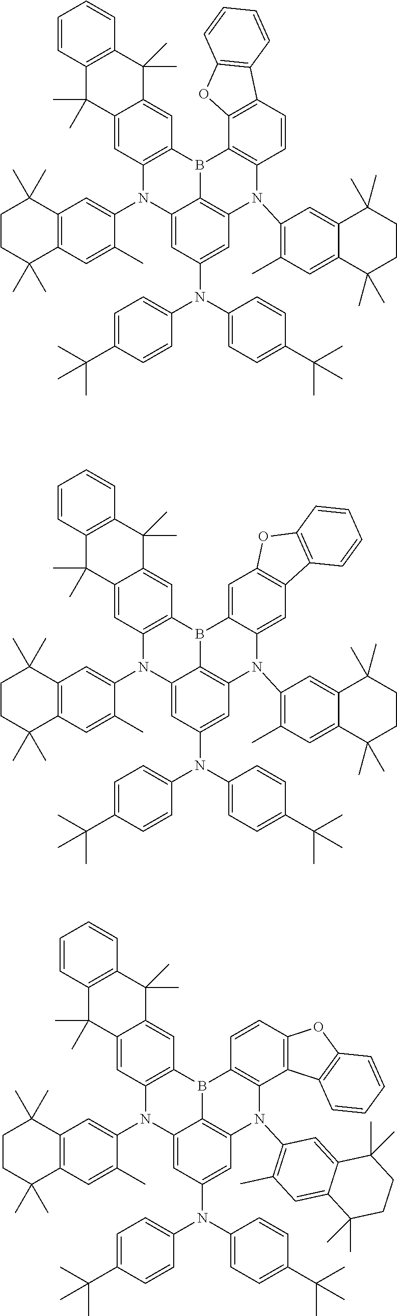 [SMILES: Cc1cc2c(cc1N1c3cc4c(cc3B3c5c1cc(N(c1ccc(C(C)(C)C)cc1)c1ccc(C(C)(C)C)cc1)cc5N(c1cc5c(cc1C)C(C)(C)CCC5(C)C)c1ccc5c(oc6ccccc65)c13)C(C)(C)c1ccccc1C4(C)C)C(C)(C)CCC2(C)C ; Cc1cc2c(cc1N1c3cc4c(cc3B3c5cc6oc7ccccc7c6cc5N(c5cc6c(cc5C)C(C)(C)CCC6(C)C)c5cc(N(c6ccc(C(C)(C)C)cc6)c6ccc(C(C)(C)C)cc6)cc1c53)C(C)(C)c1ccccc1C4(C)C)C(C)(C)CCC2(C)C ; Cc1cc2c(cc1N1c3cc4c(cc3B3c5ccc6oc7ccccc7c6c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

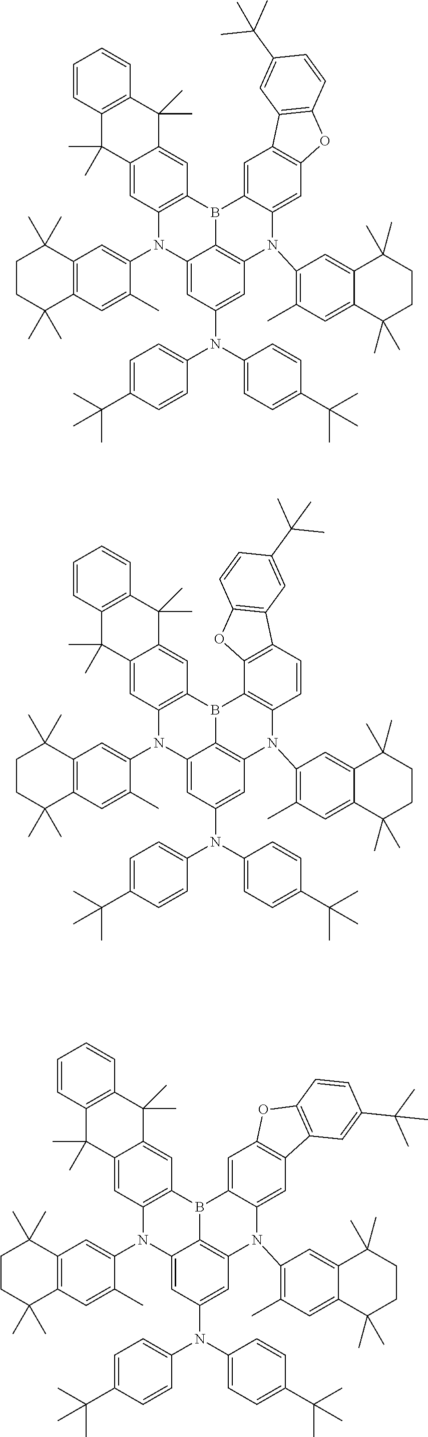

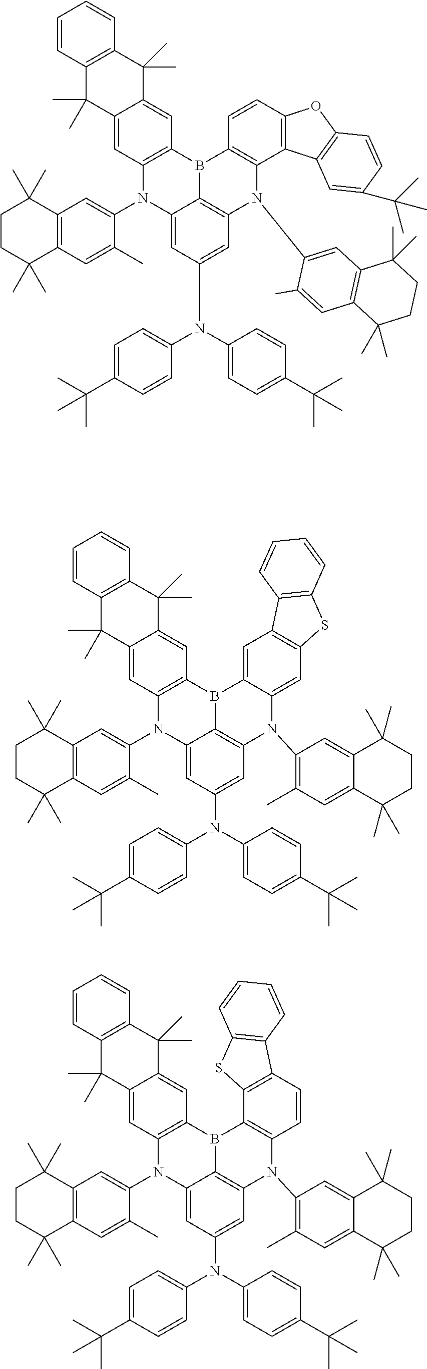

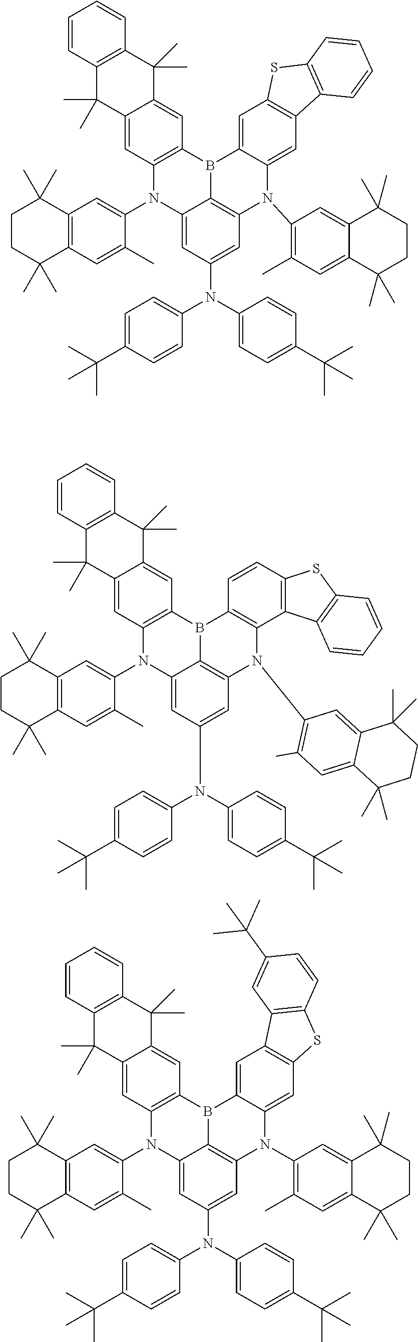

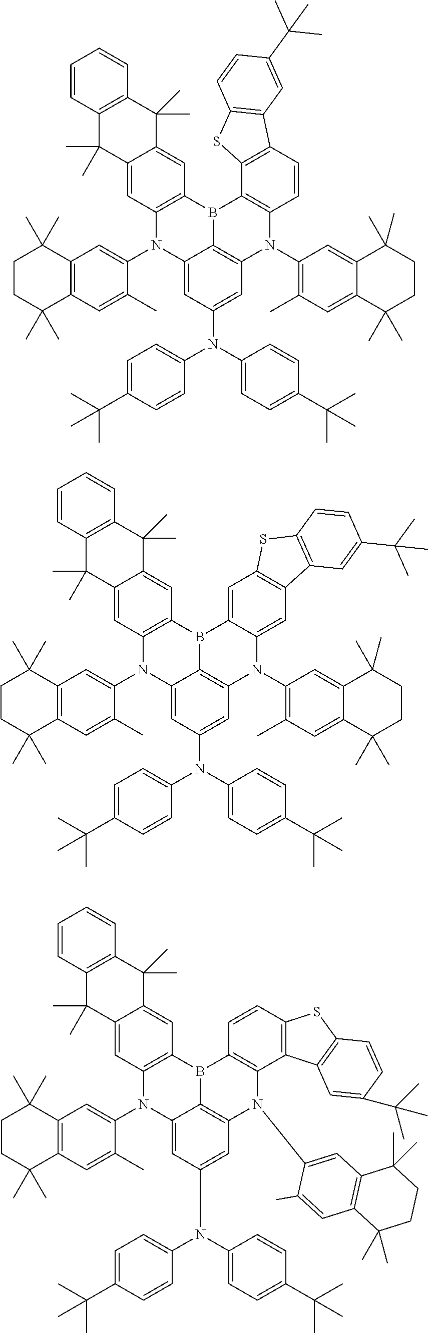

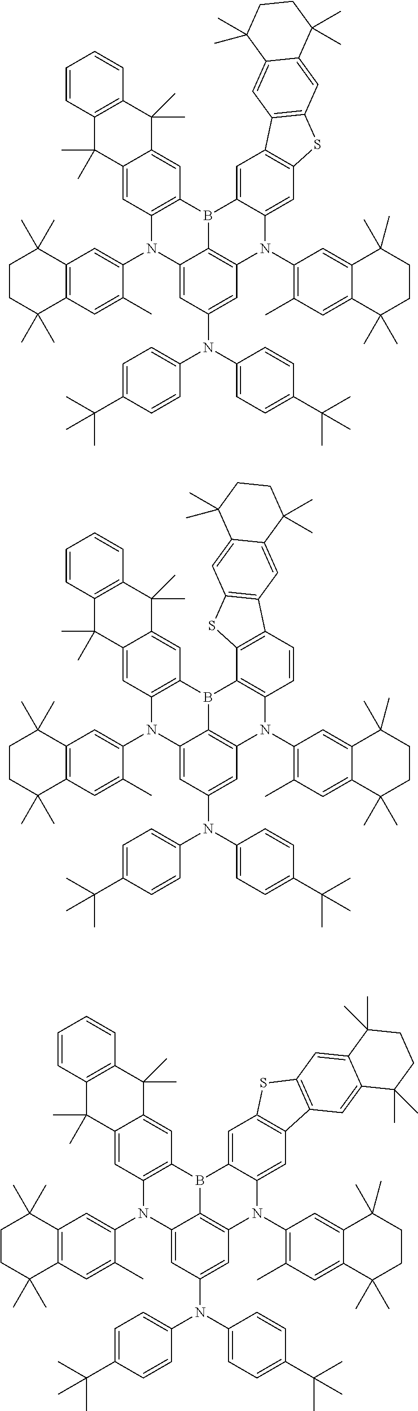

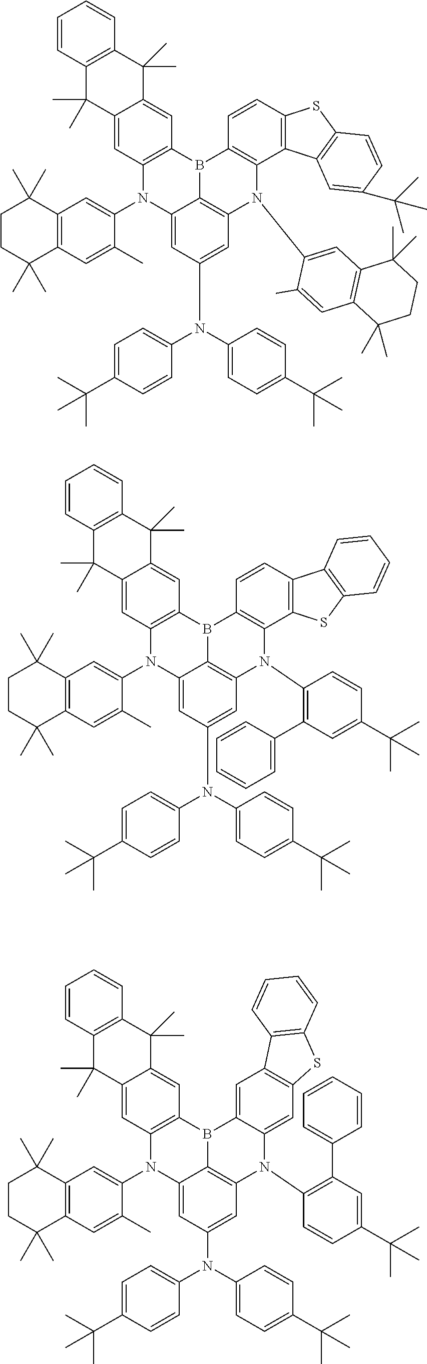

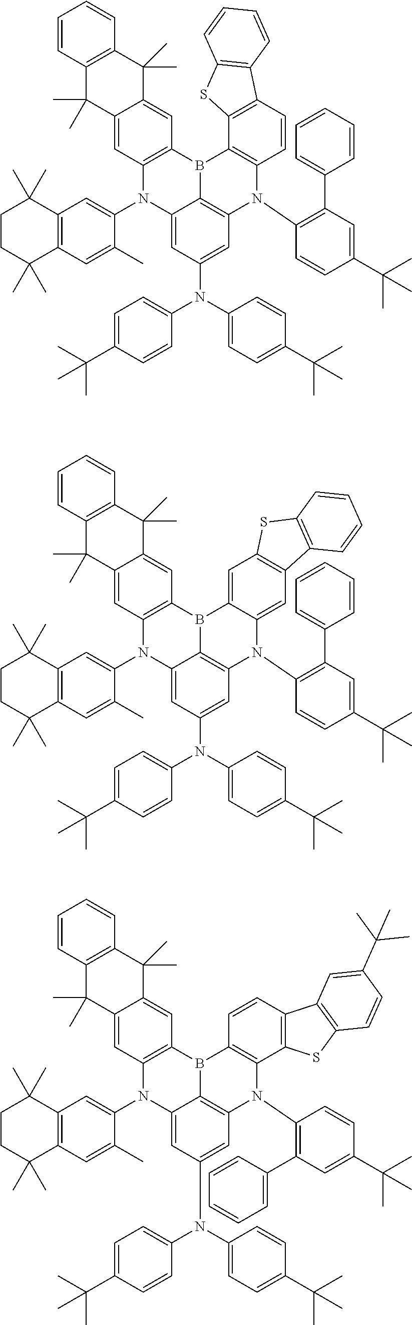

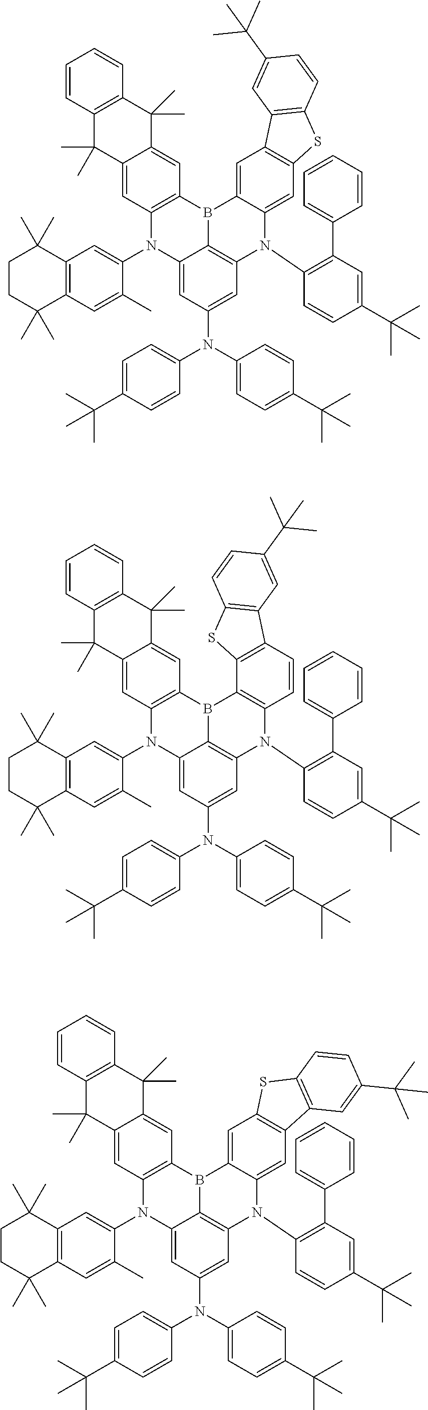

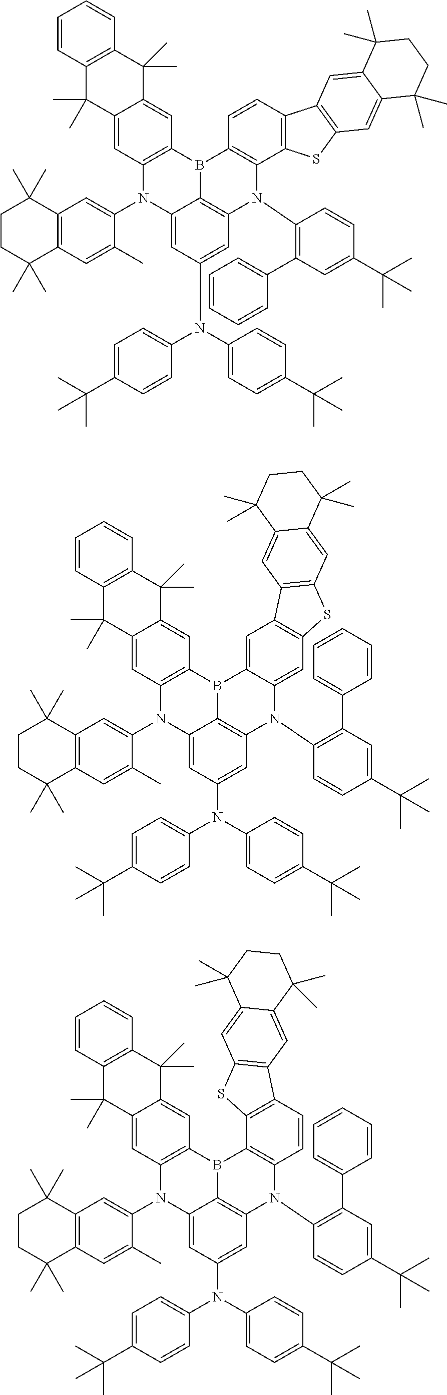

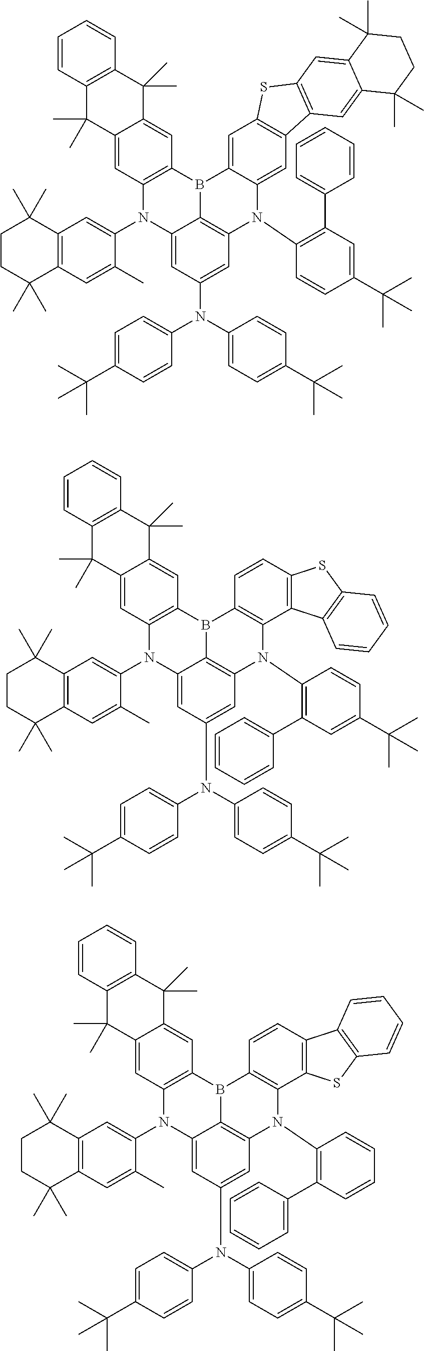

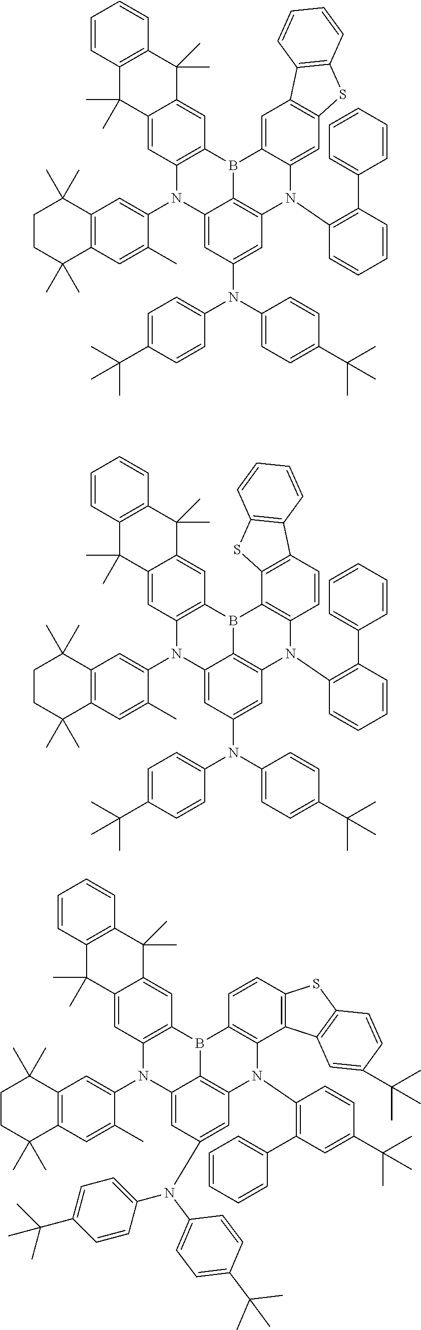

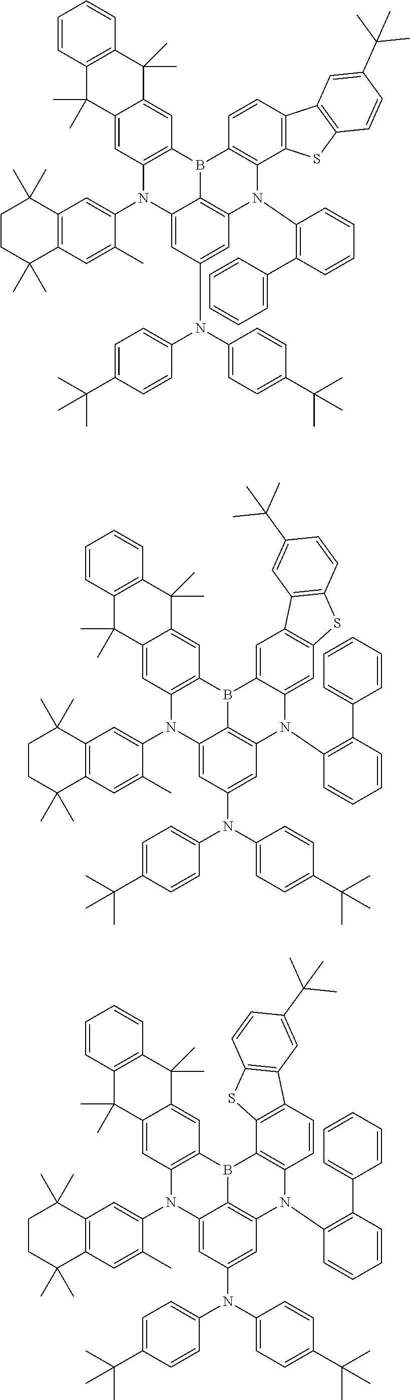

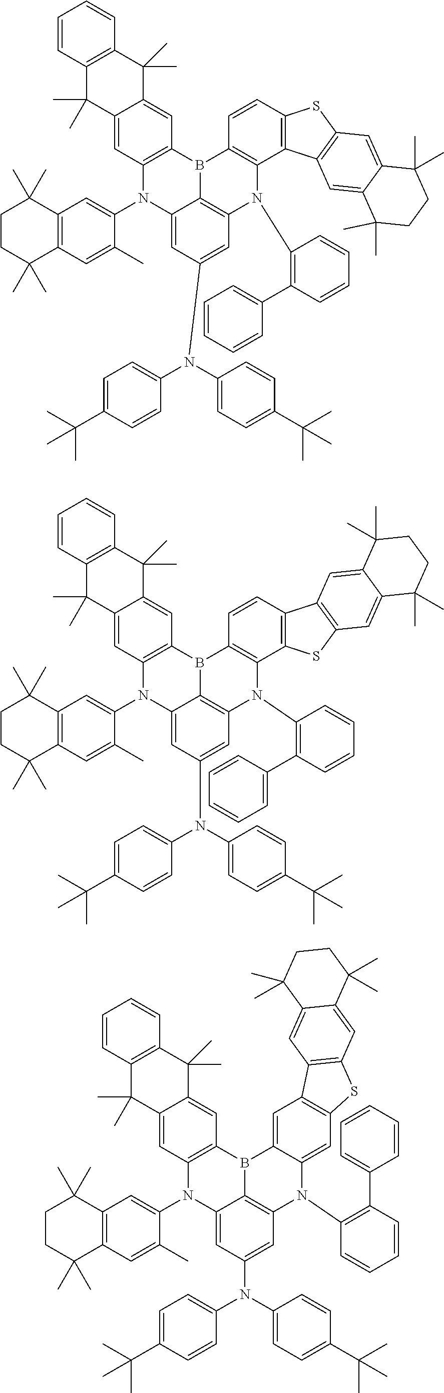

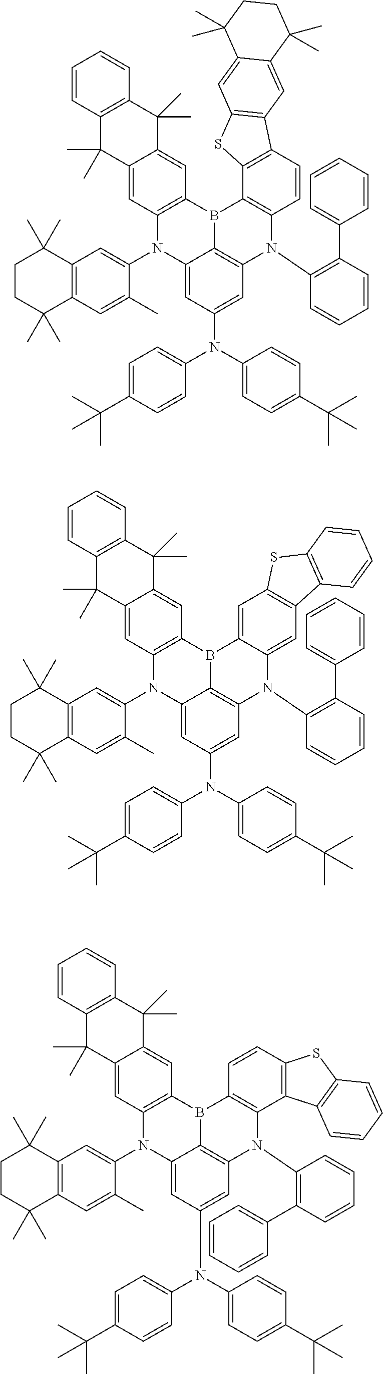

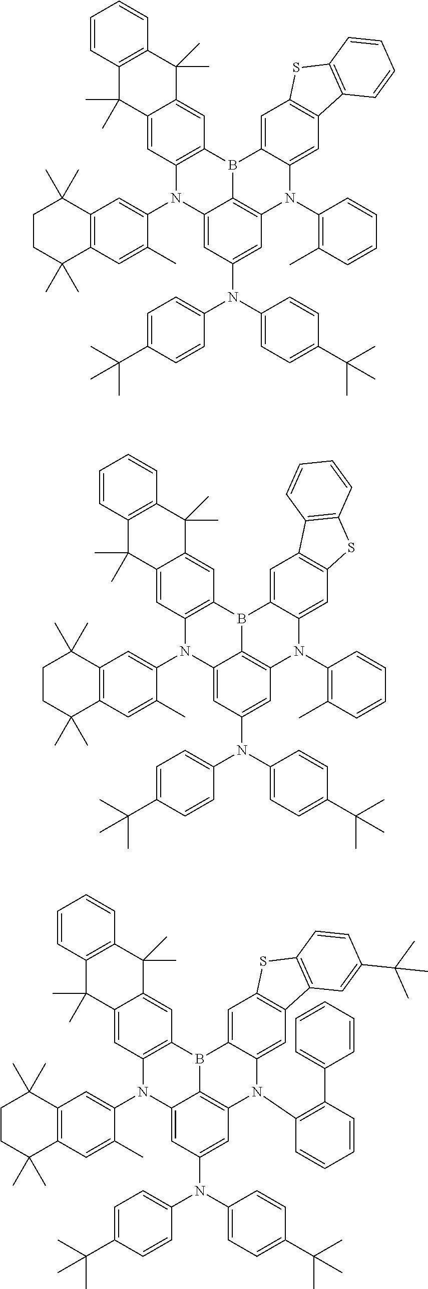 [SMILES: Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)c1ccccc1C5(C)C)sc1ccccc13 ; Cc1ccccc1N1c2cc3sc4ccccc4c3cc2B2c3cc4c(cc3N(c3cc5c(cc3C)C(C)(C)CCC5(C)C)c3cc(N(c5ccc(C(C)(C)C)cc5)c5ccc(C(C)(C)C)cc5)cc1c32)C(C)(C)c1ccccc1C4(C)C ; Cc1cc2c(cc1N1c3cc4c(cc3B3c5cc6sc7ccc(C(C)(C)C)cc7c6cc5N(c5ccccc5-c5ccccc5)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

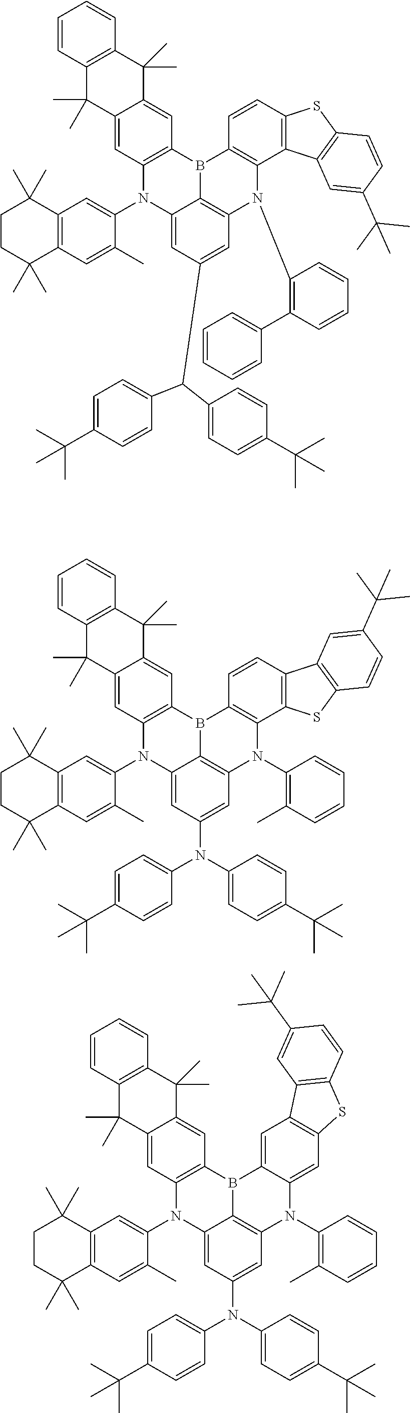

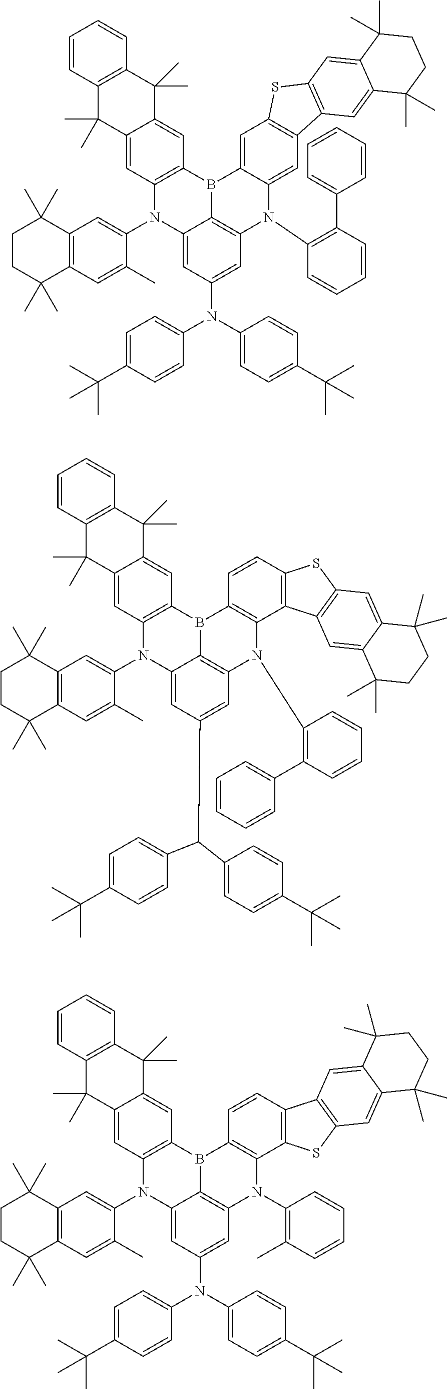

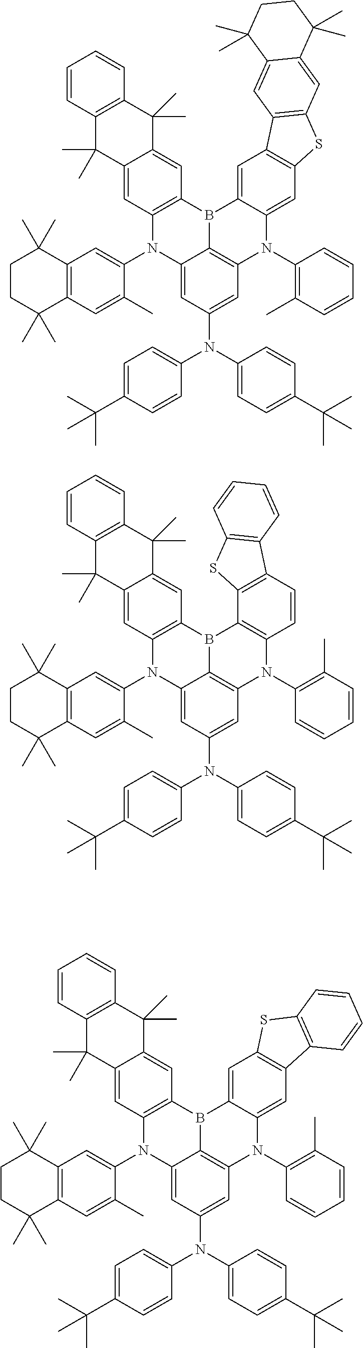

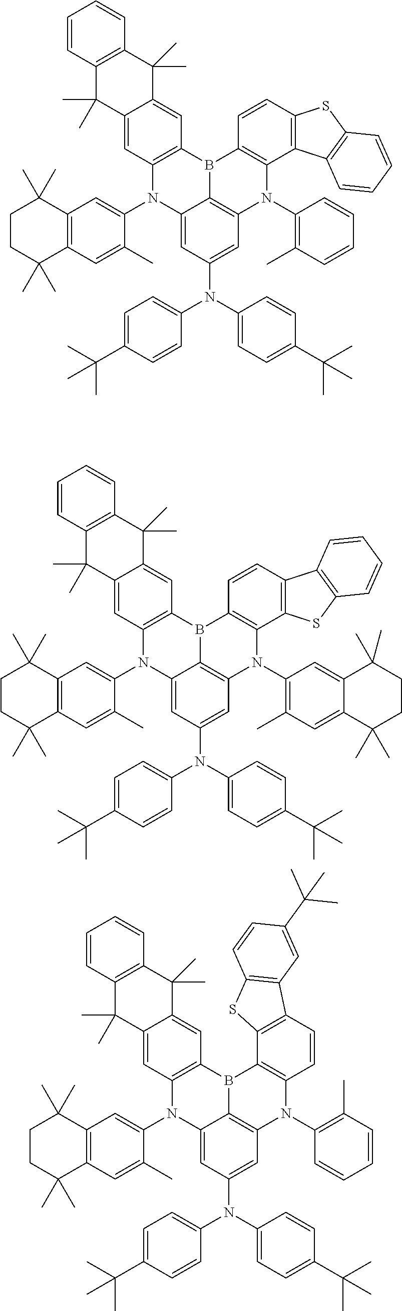

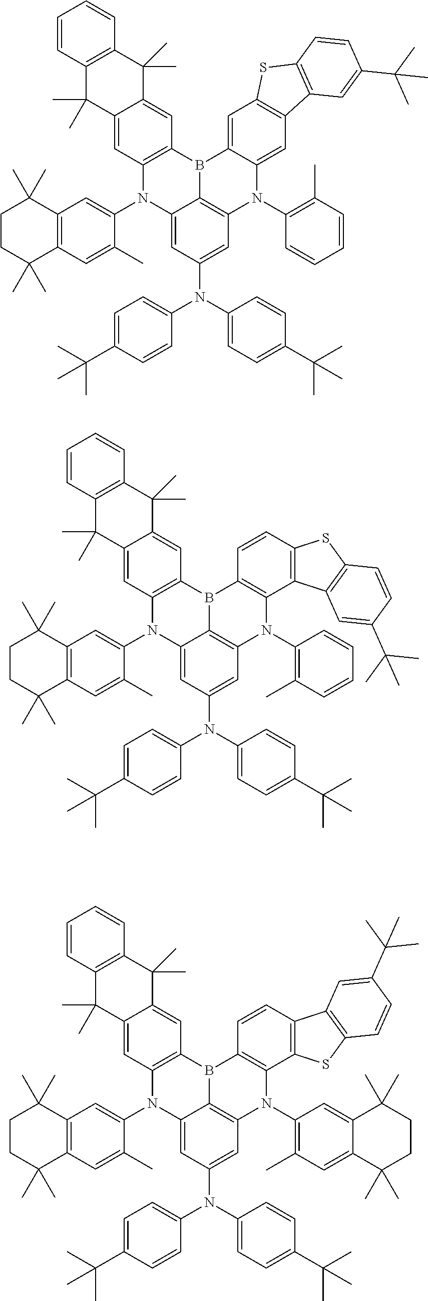

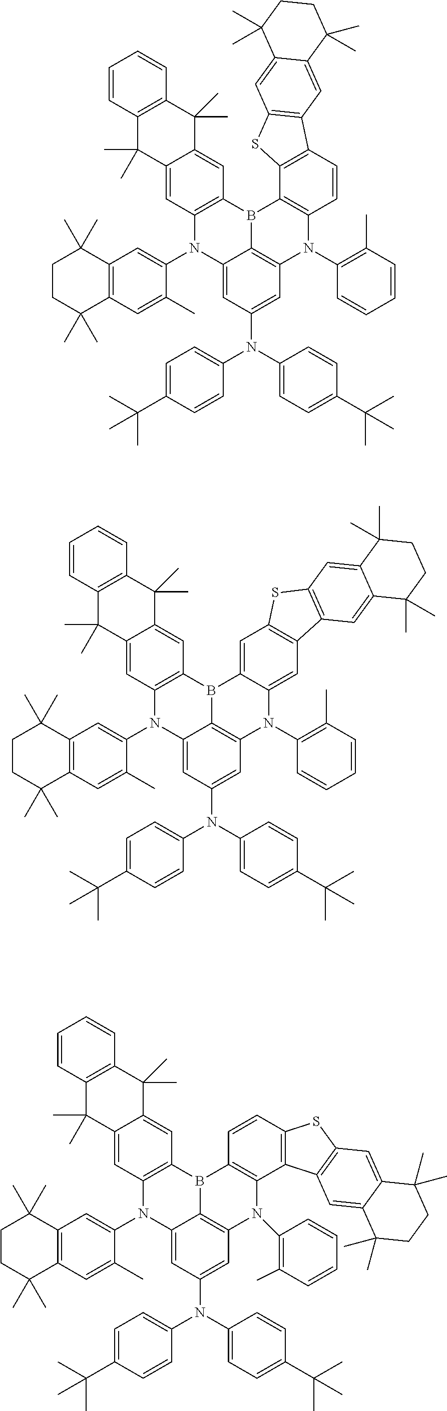 [SMILES: Cc1cc2c(cc1N1c3cc4c(cc3B3c5c1cc(N(c1ccc(C(C)(C)C)cc1)c1ccc(C(C)(C)C)cc1)cc5N(c1ccccc1C)c1ccc5c(sc6cc7c(cc65)C(C)(C)CCC7(C)C)c13)C(C)(C)c1ccccc1C4(C)C)C(C)(C)CCC2(C)C ; Cc1ccccc1N1c2cc3c(cc2B2c4cc5c(cc4N(c4cc6c(cc4C)C(C)(C)CCC6(C)C)c4cc(N(c6ccc(C(C)(C)C)cc6)c6ccc(C(C)(C)C)cc6)cc1c42)C(C)(C)c1ccccc1C5(C)C)sc1cc2c(cc13)C(C)(C)CCC2(C)C ; Cc1cc2c(cc1N1c3cc4c(cc3B3c5ccc6sc7cc8c(cc7c6c5N(c5ccccc5C)c5cc(N(c6ccc(C(C)(C)C)cc6)c6ccc(C(C)(C)C)cc6)cc1c53)C(C)(C)CCC8(C)C)C(C)(C)c1ccccc1C4(C)C)C(C)(C)CCC2(C)C]

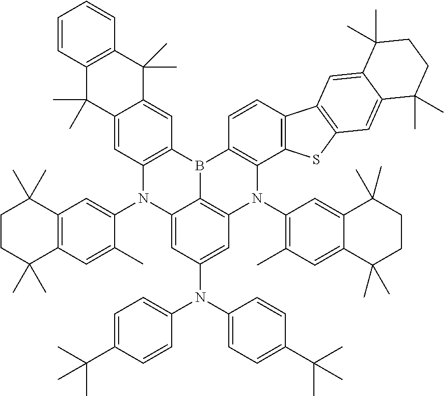 [SMILES: Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(N(c6ccc(C(C)(C)C)cc6)c6ccc(C(C)(C)C)cc6)cc1c53)C(C)(C)c1ccccc1C4(C)C)C(C)(C)CCC2(C)C]

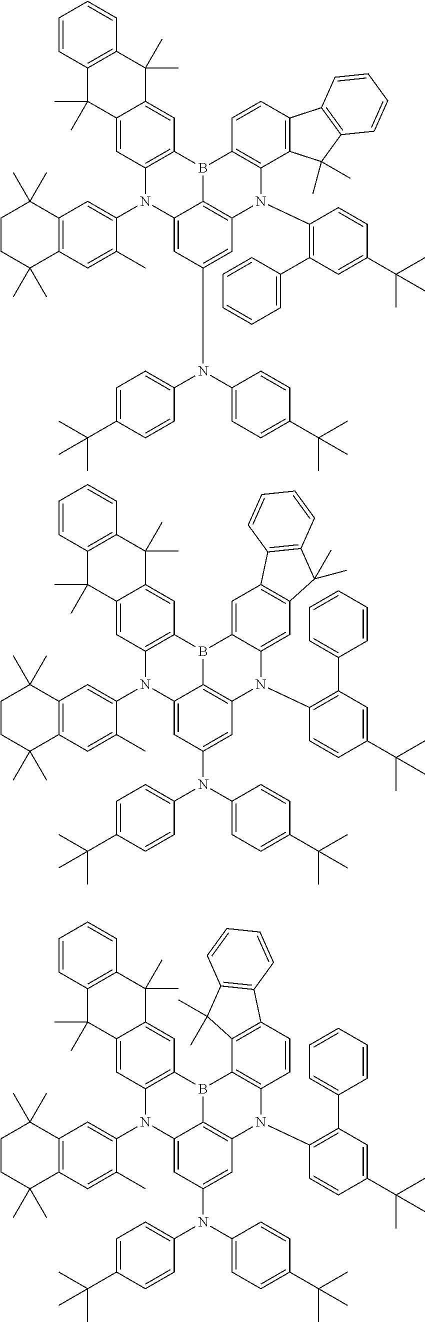

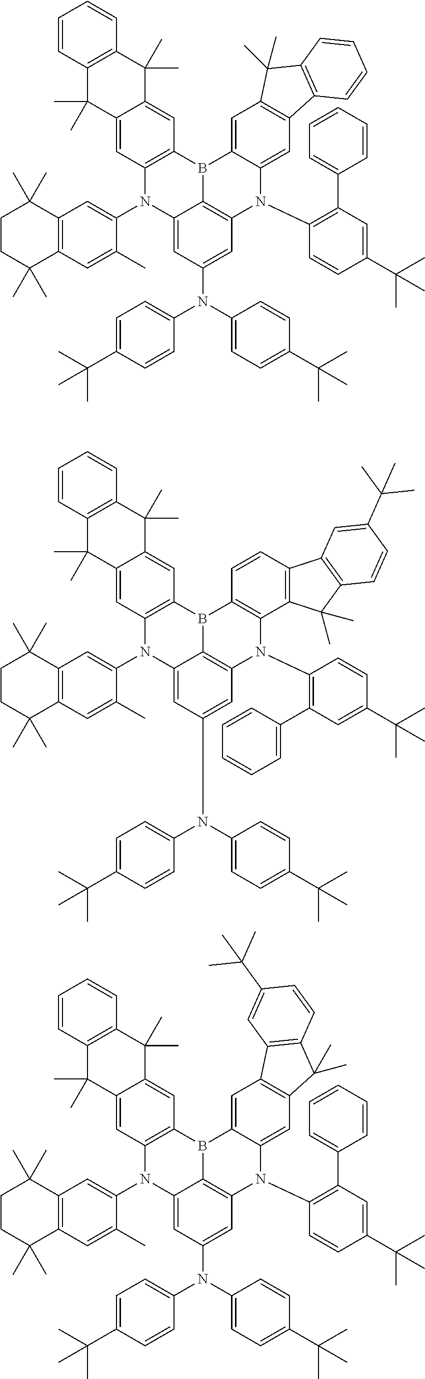

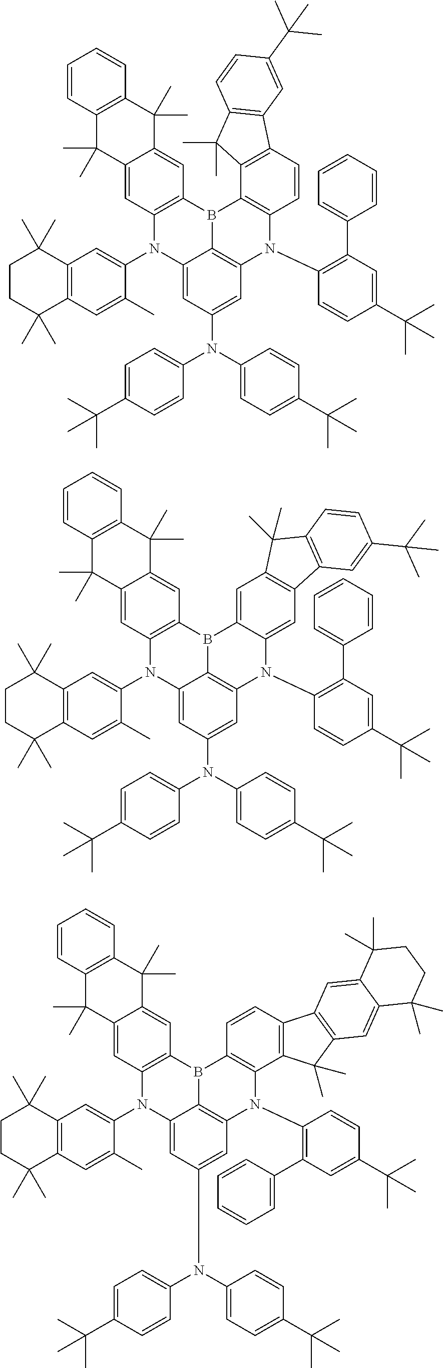

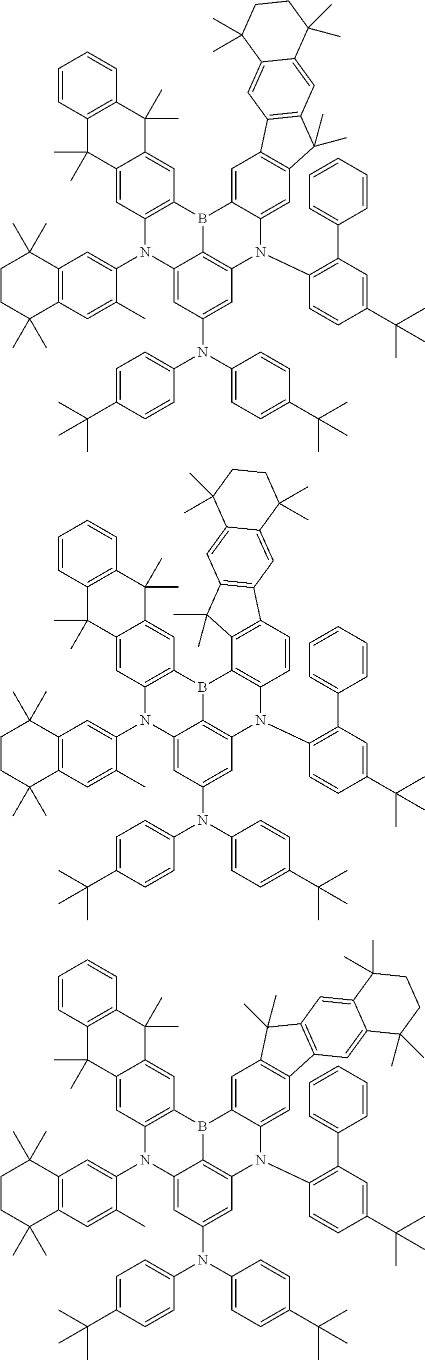

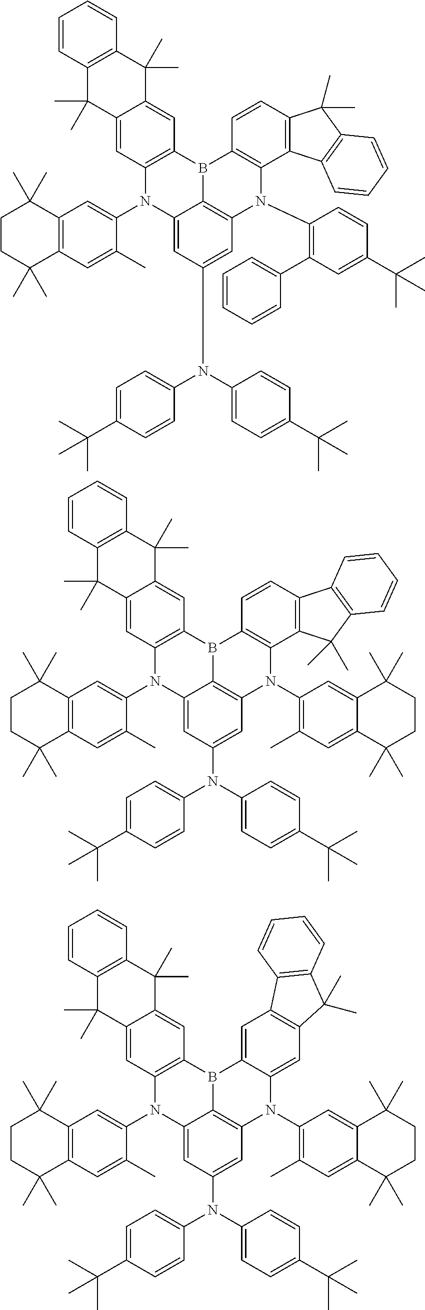

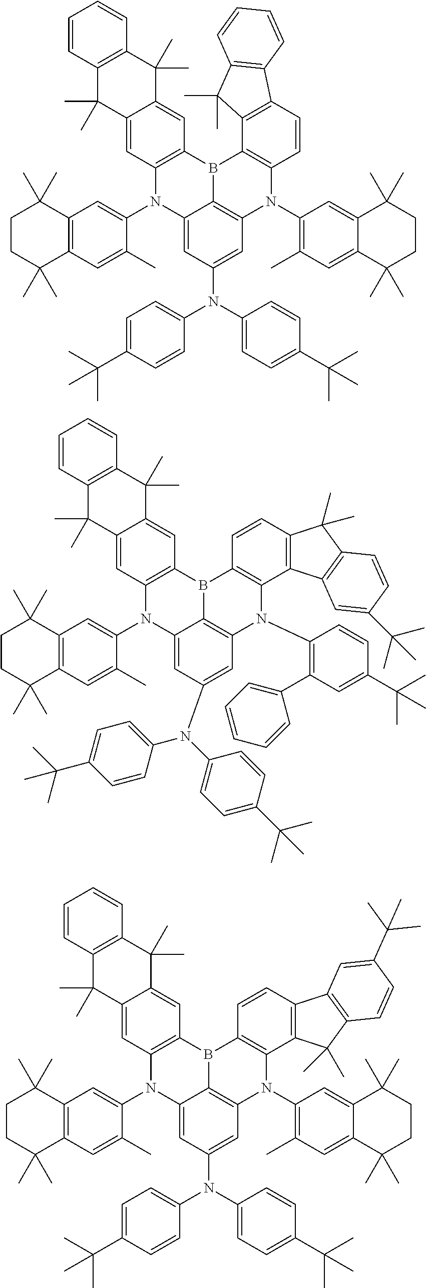

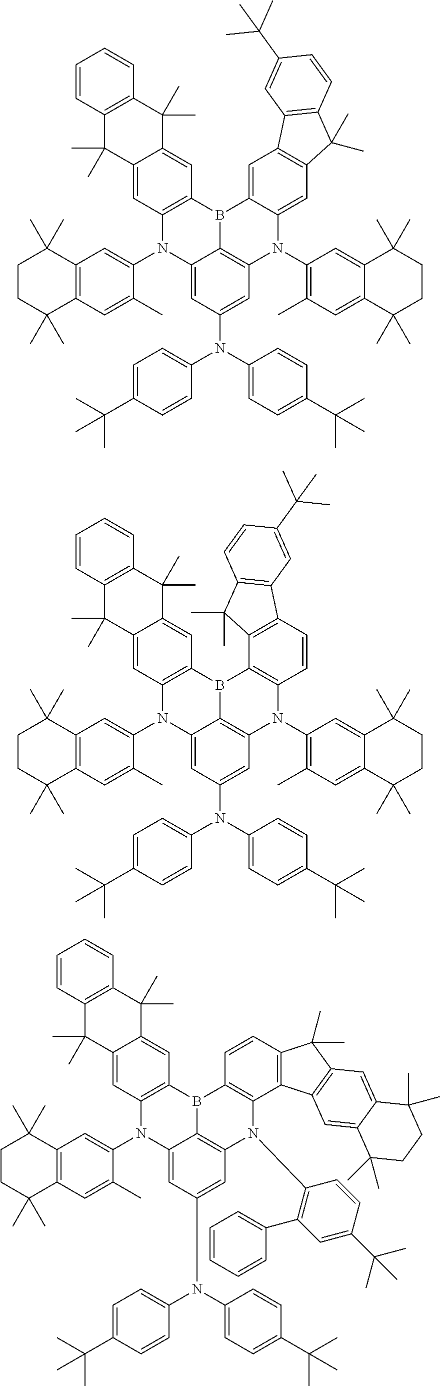

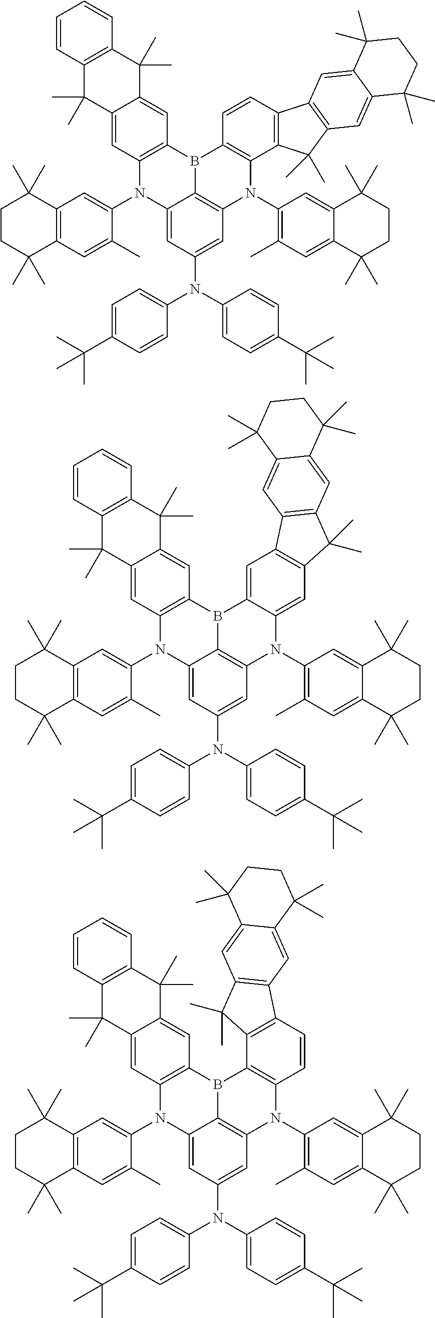

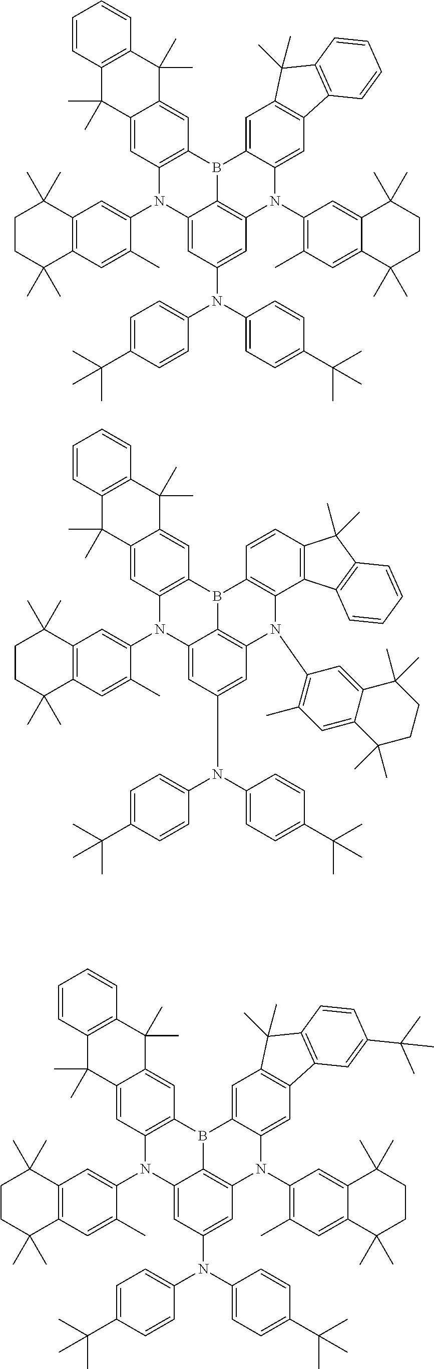

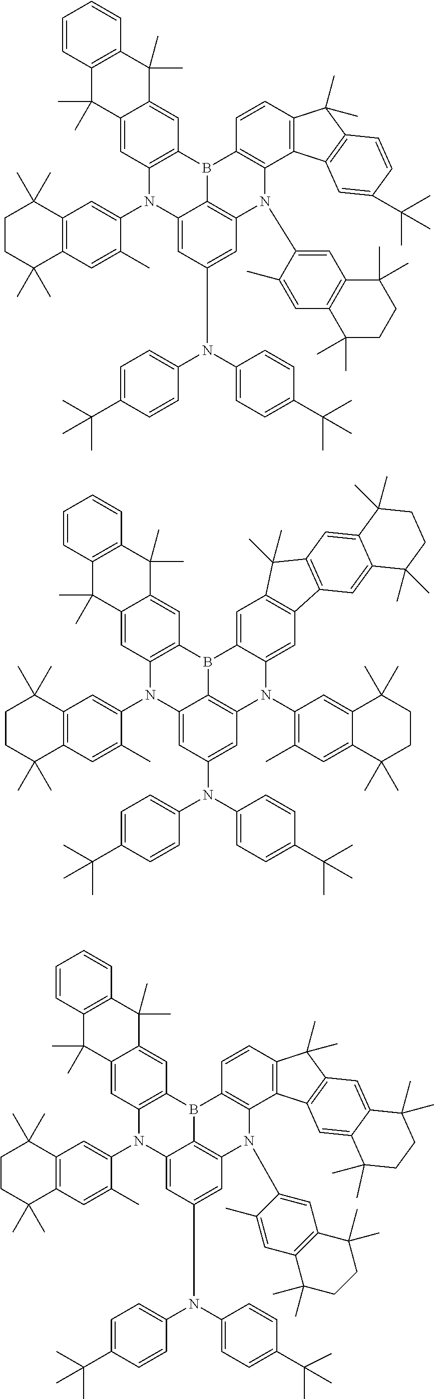

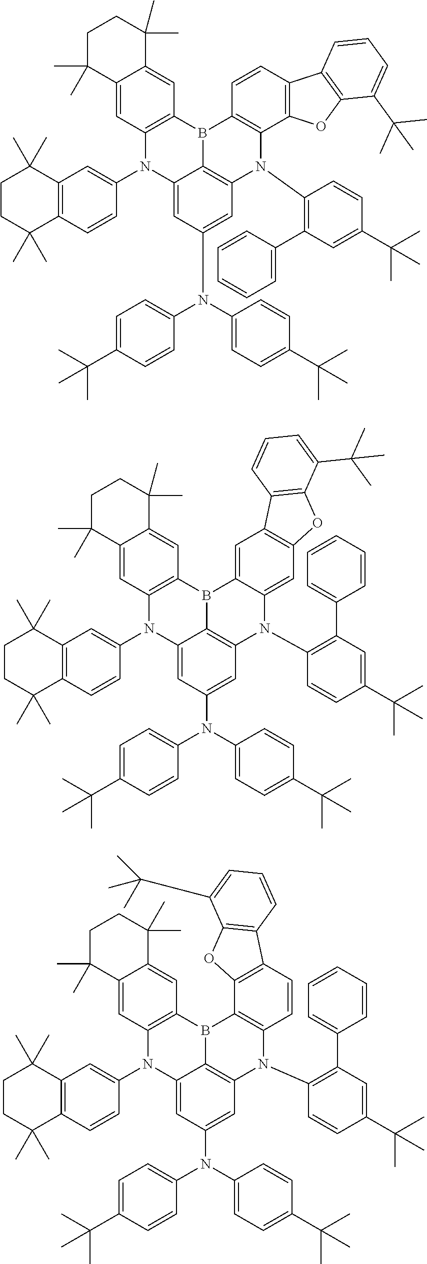

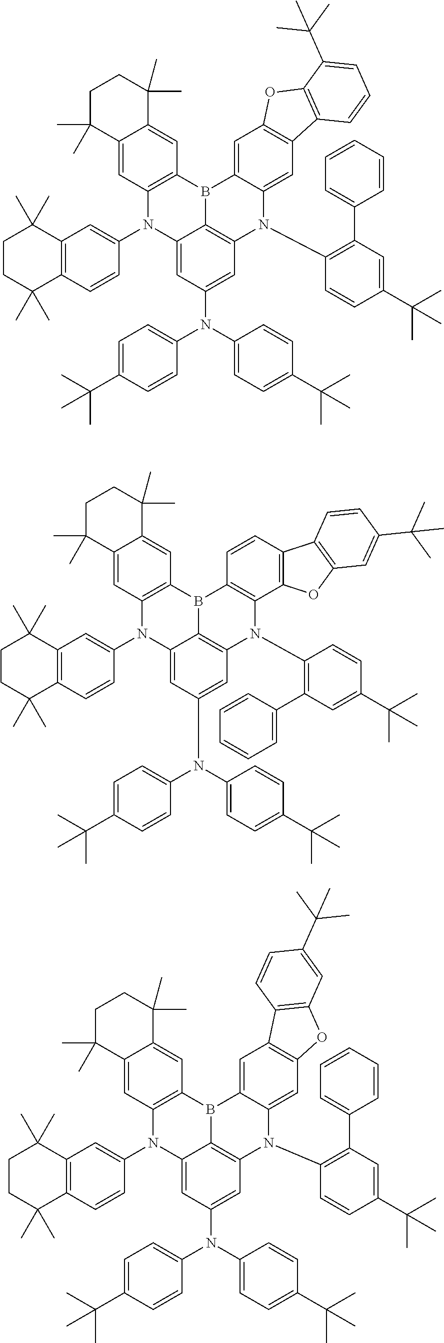

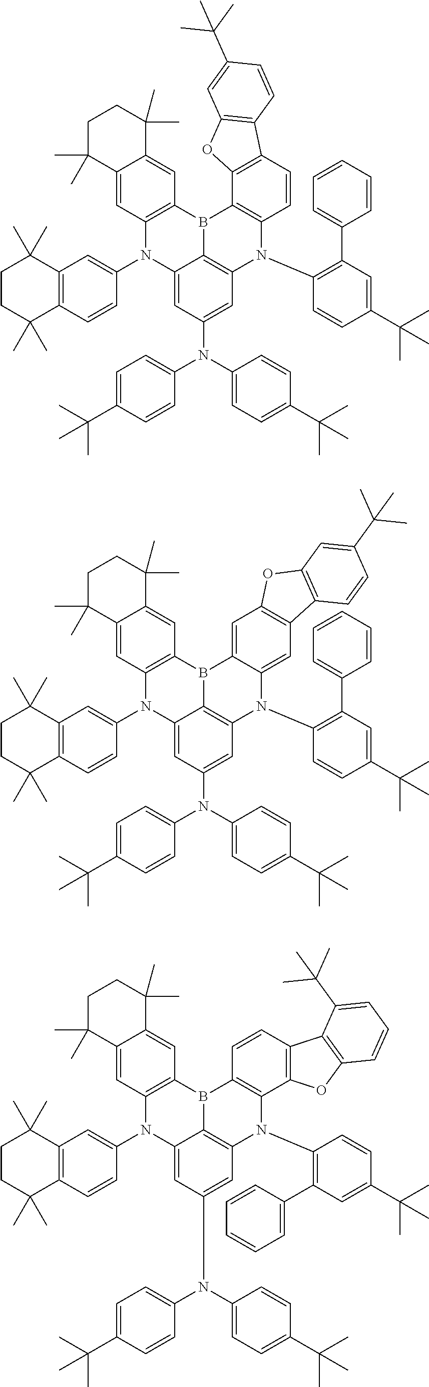

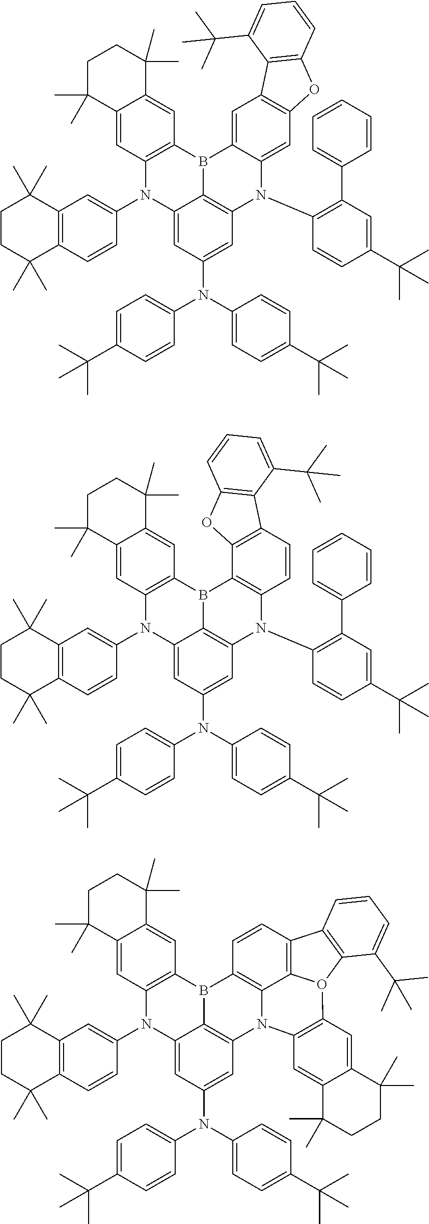

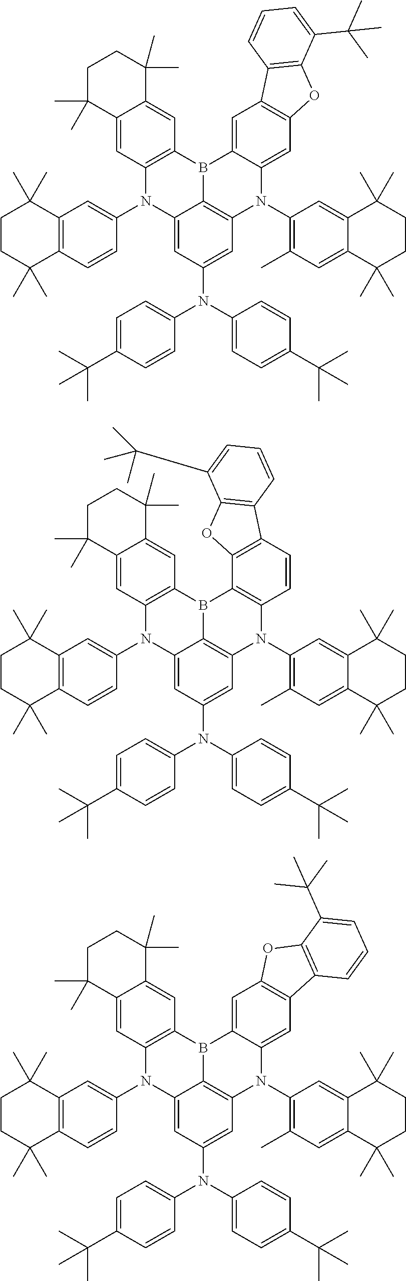

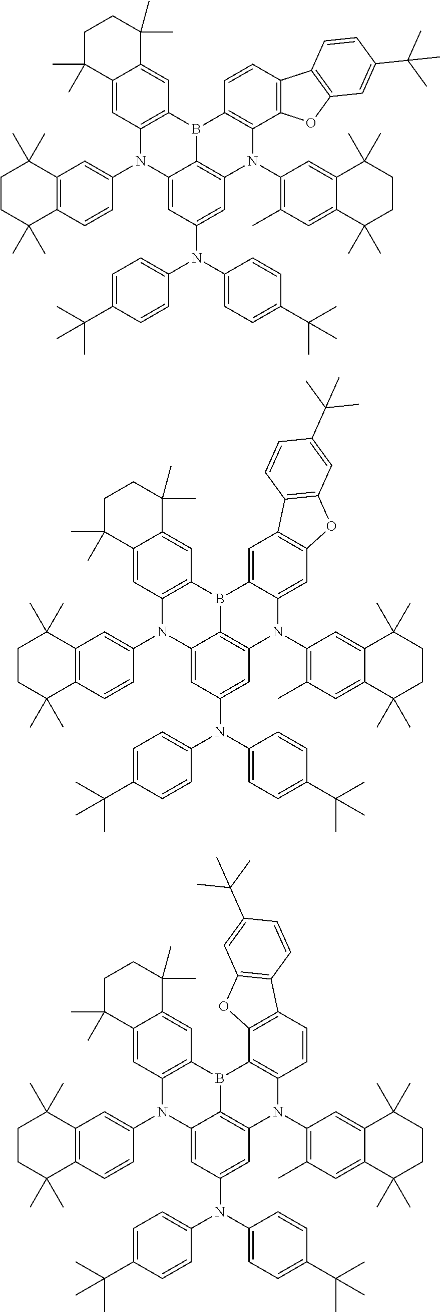

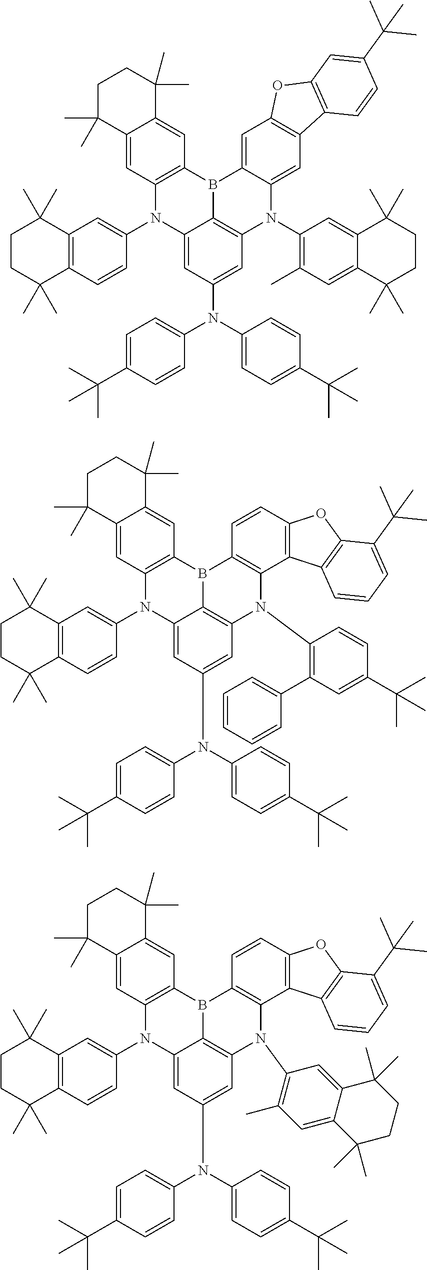

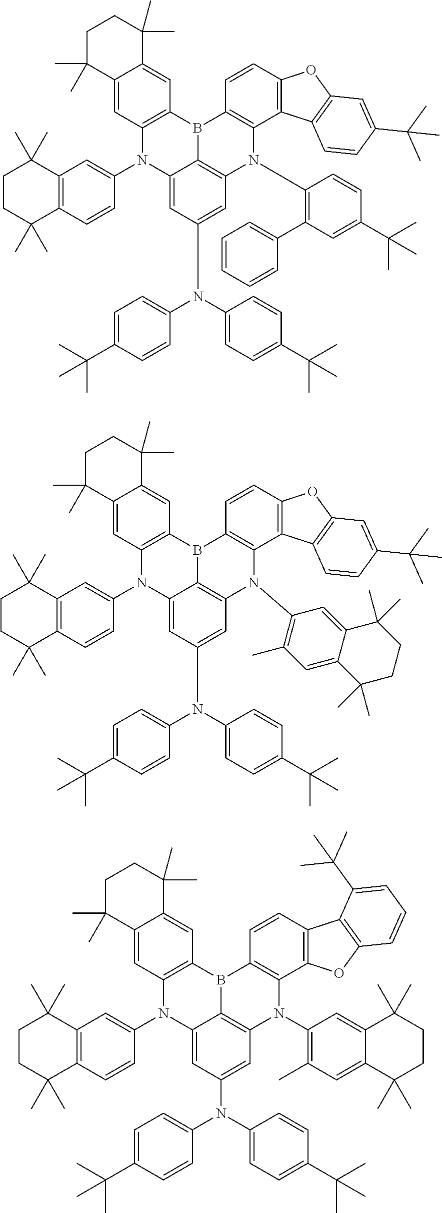

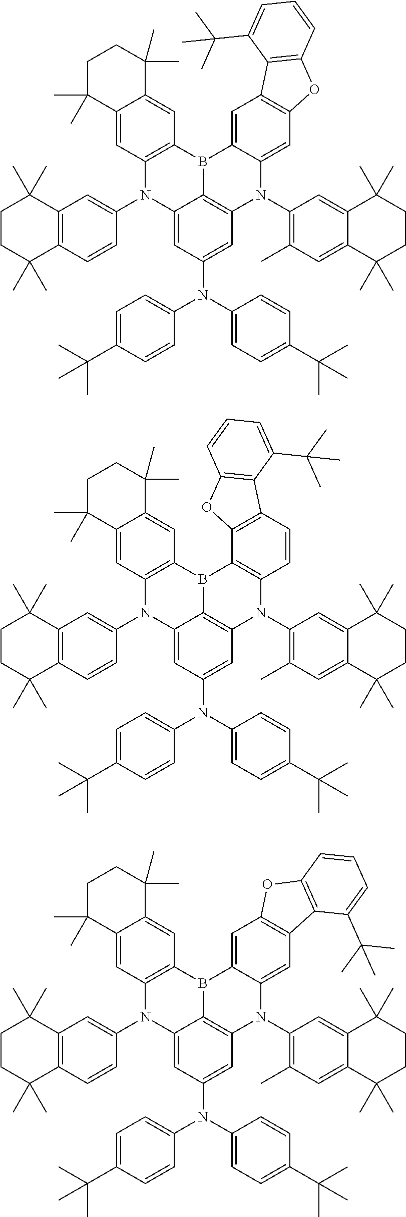

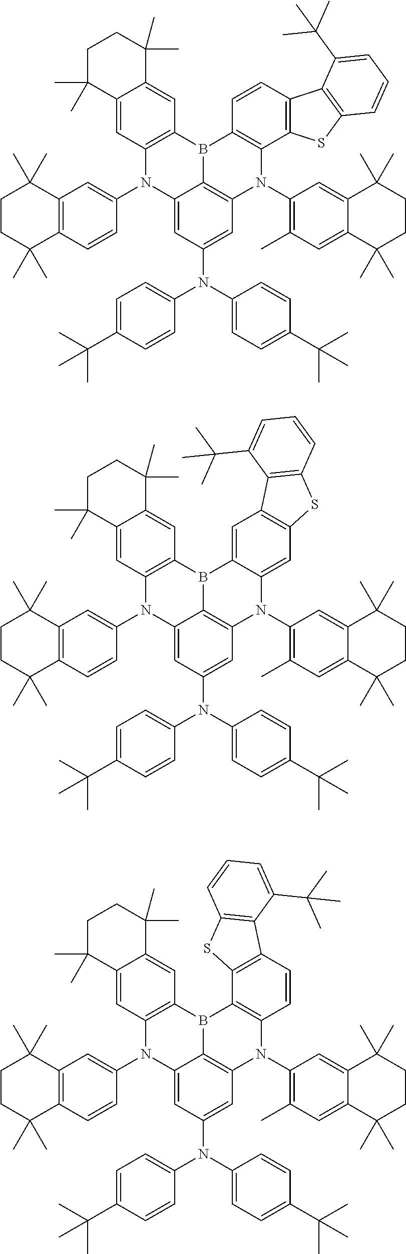

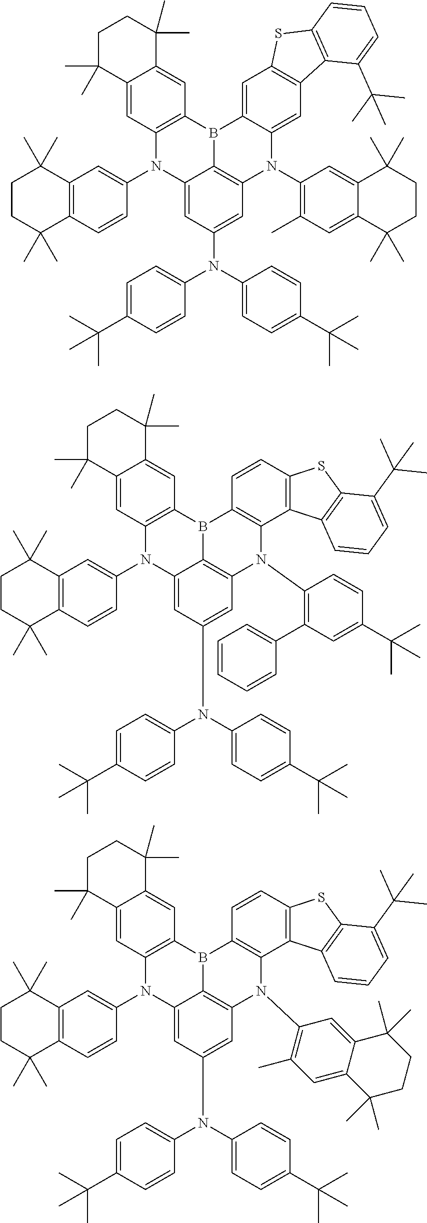

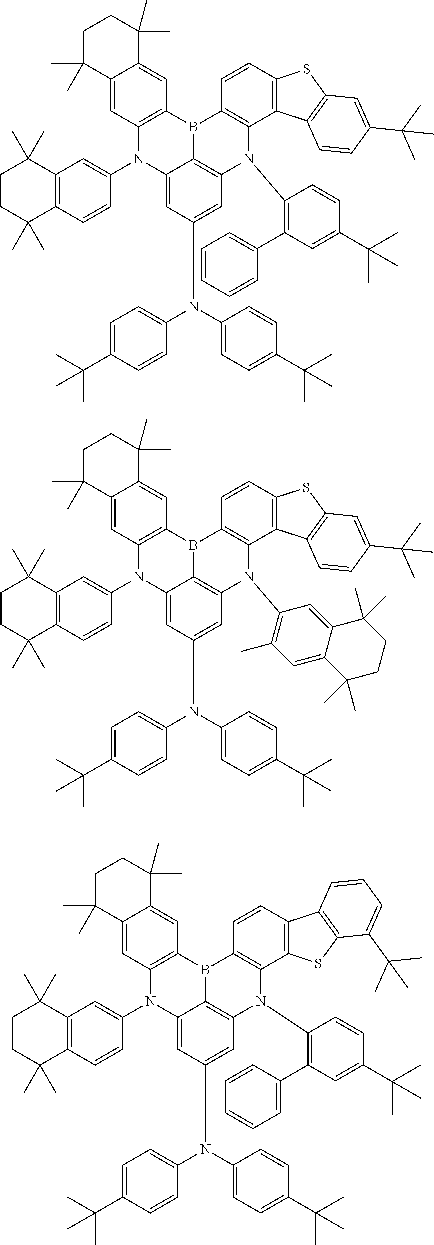

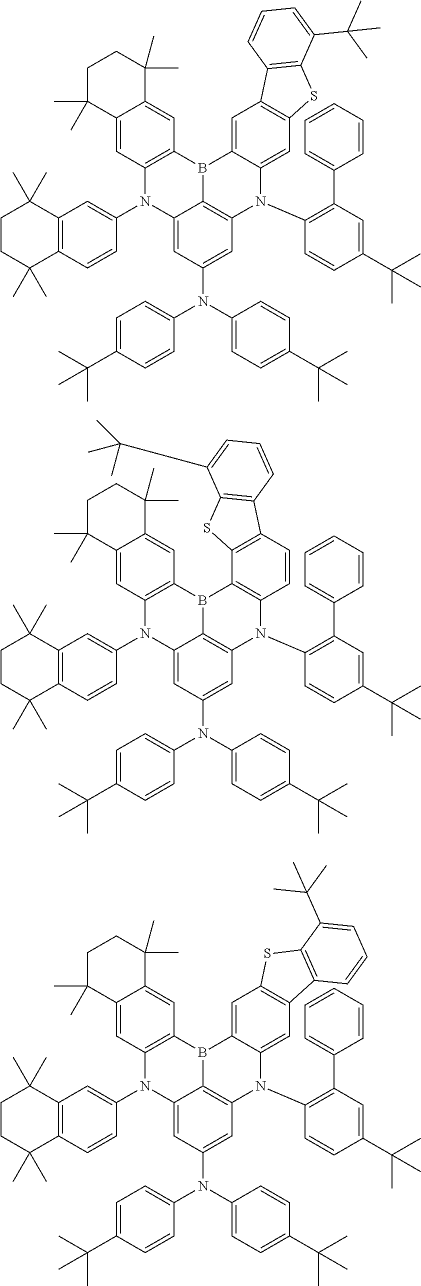

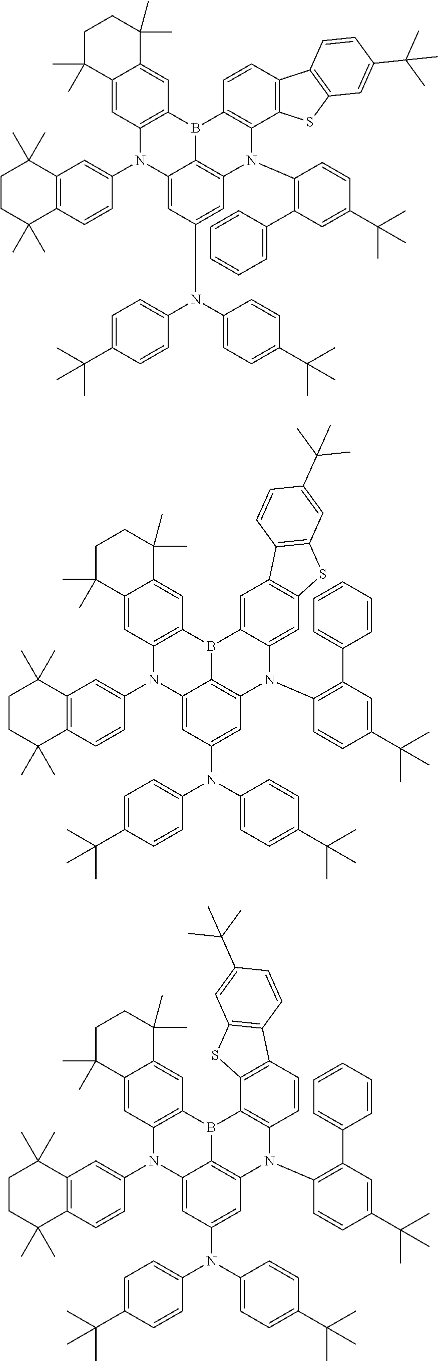

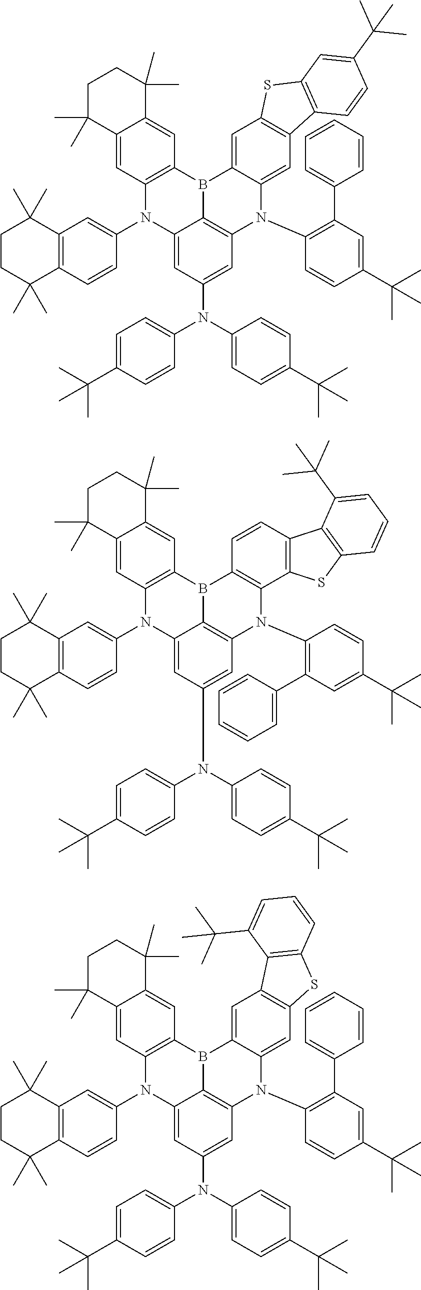

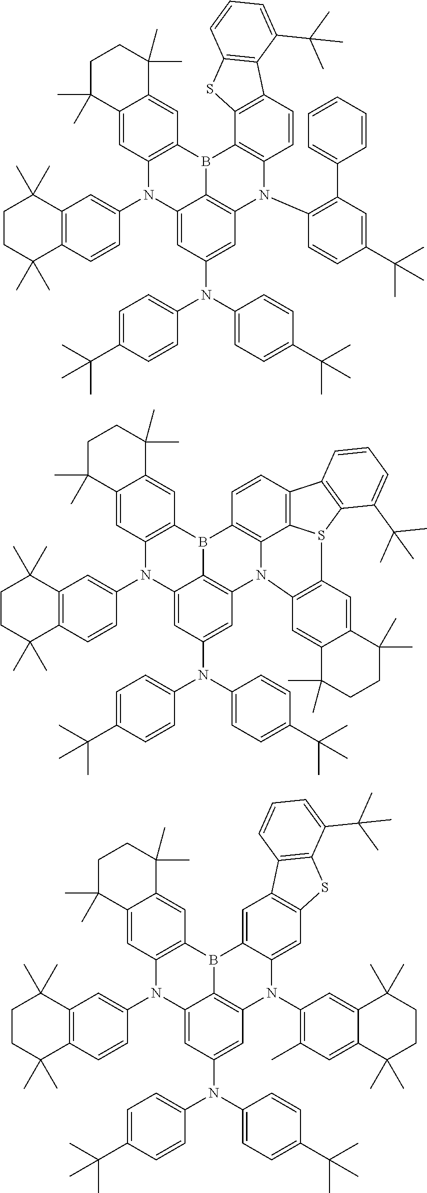

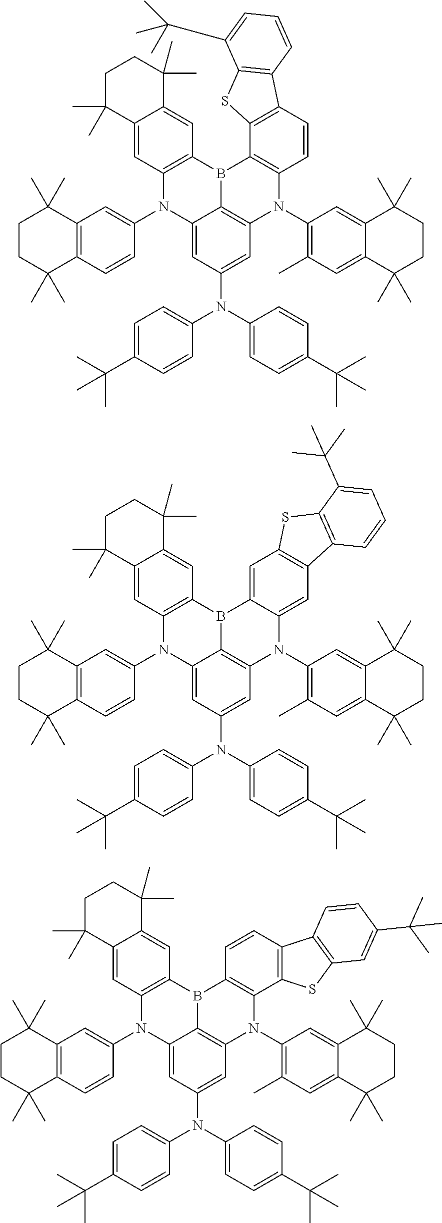

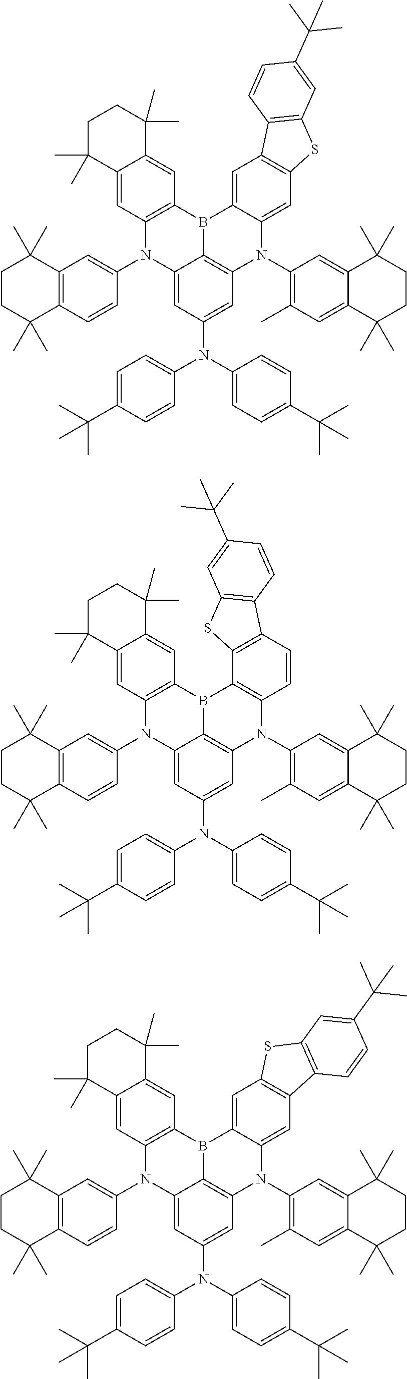

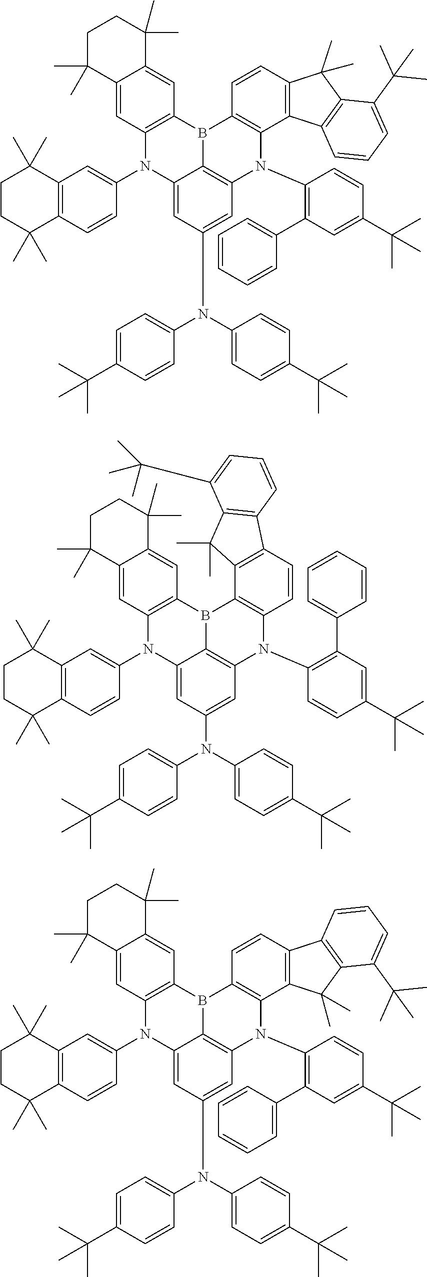

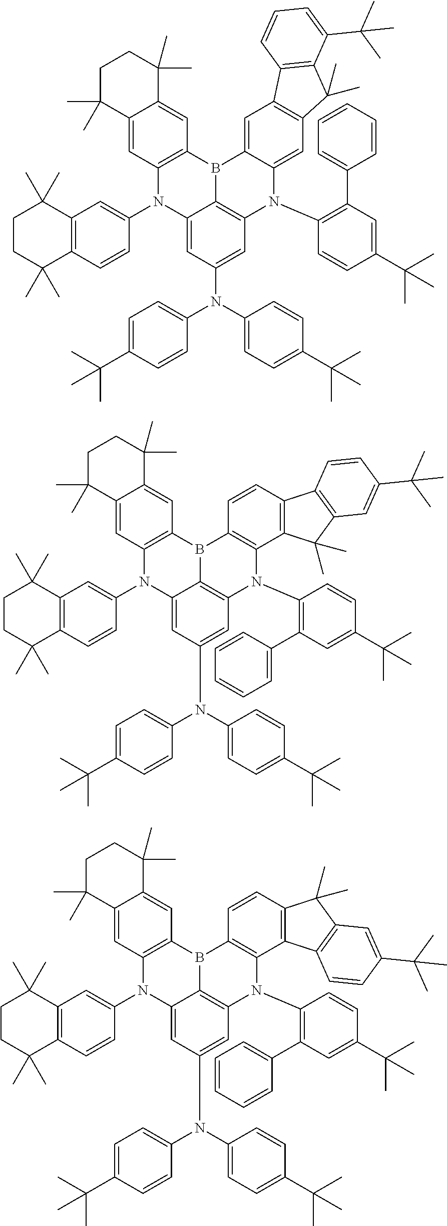

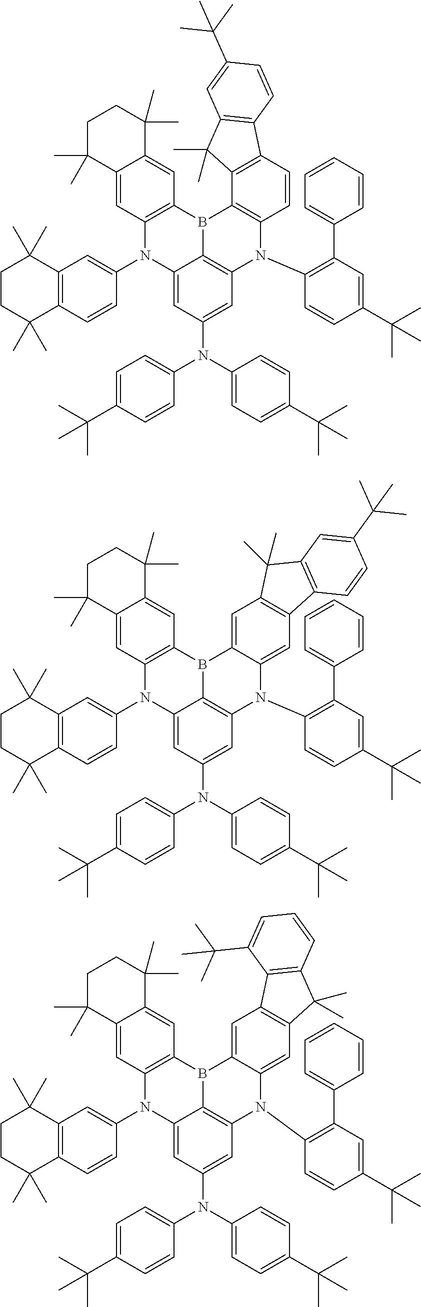

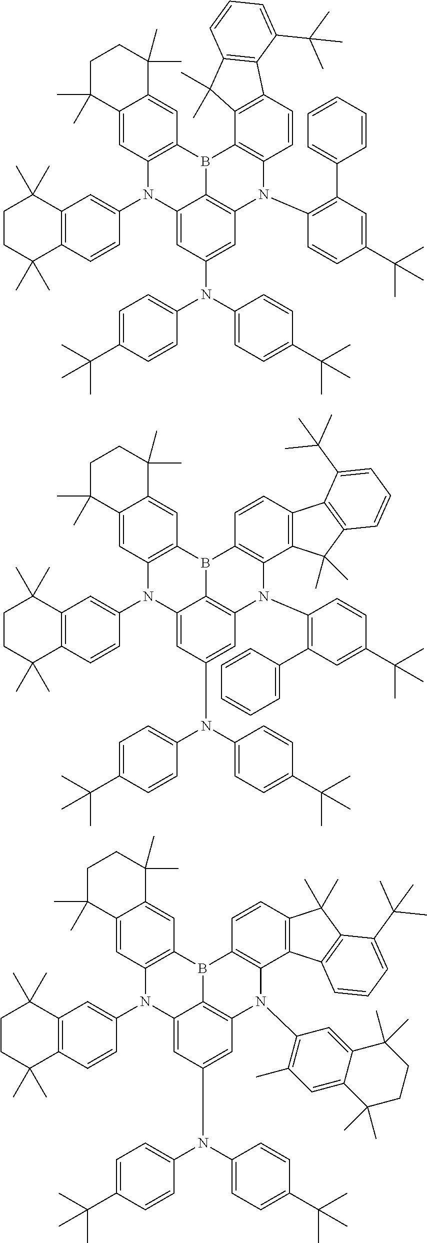

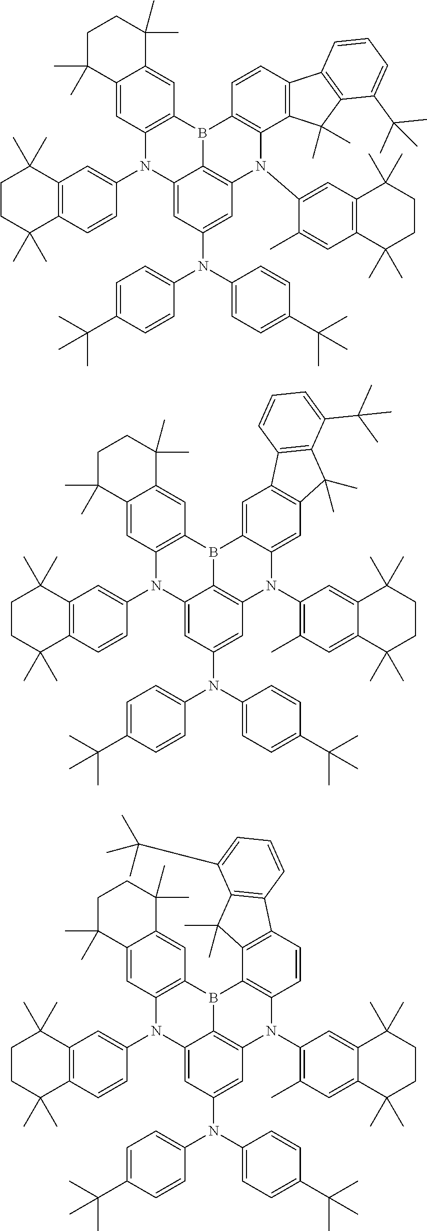

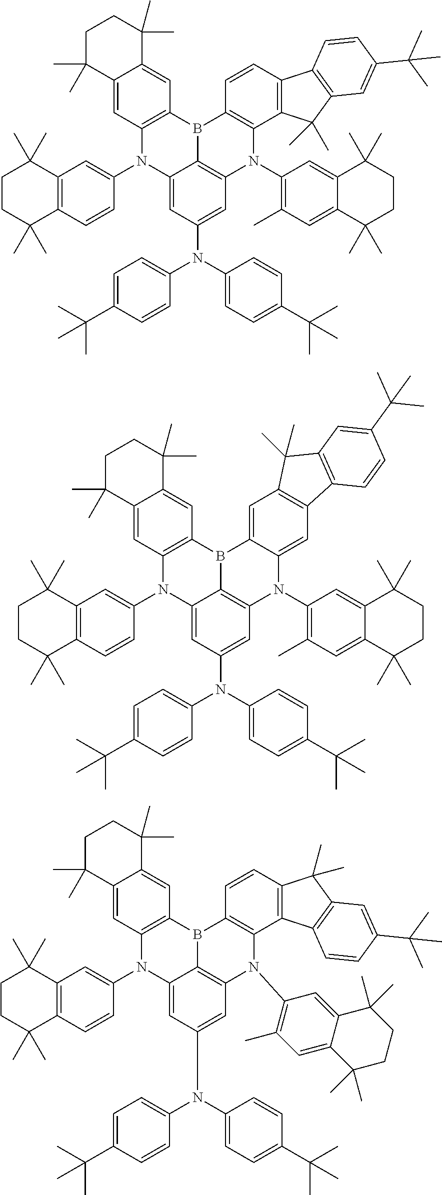

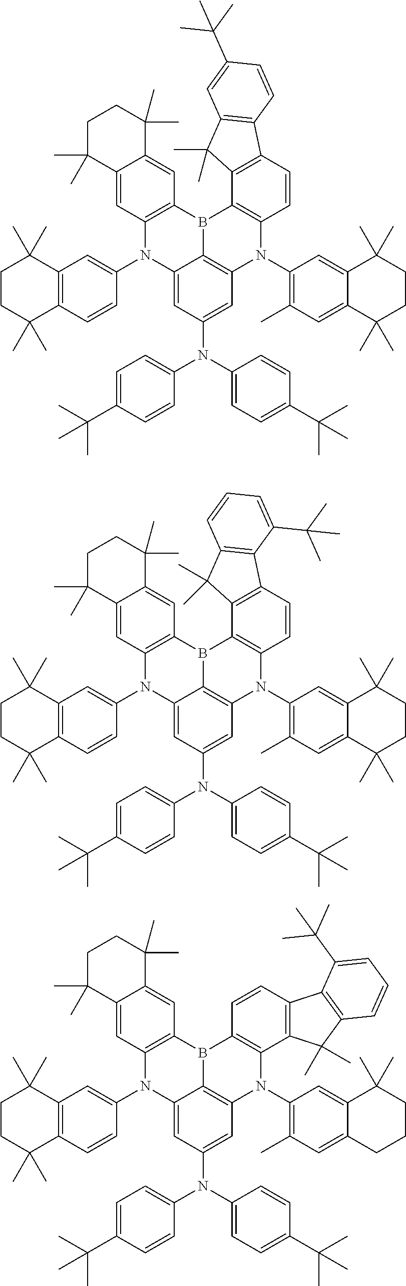

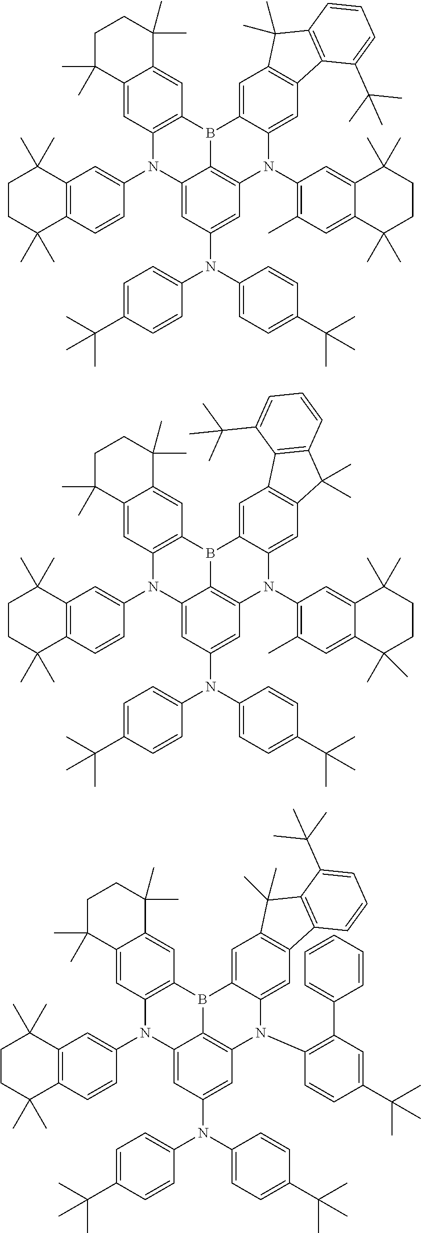

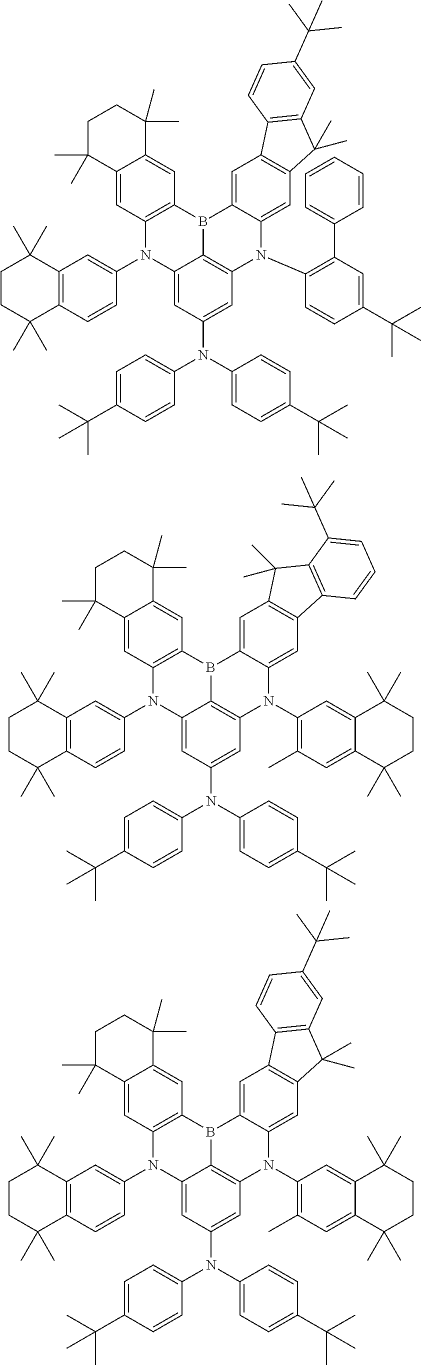

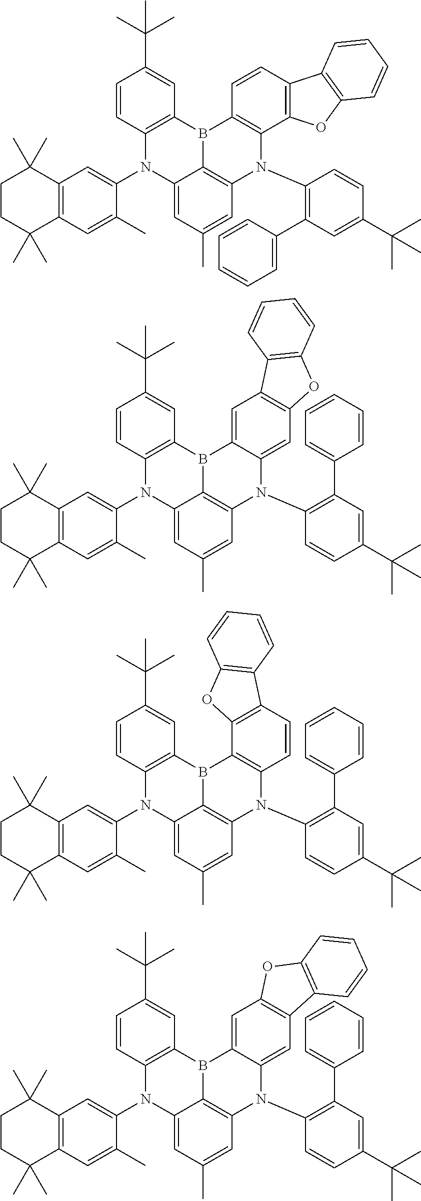

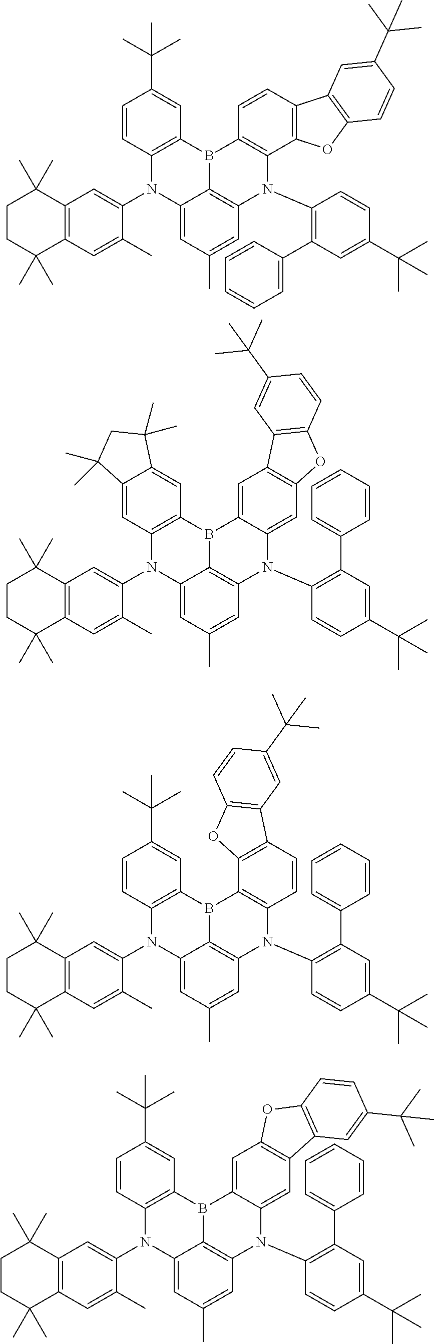

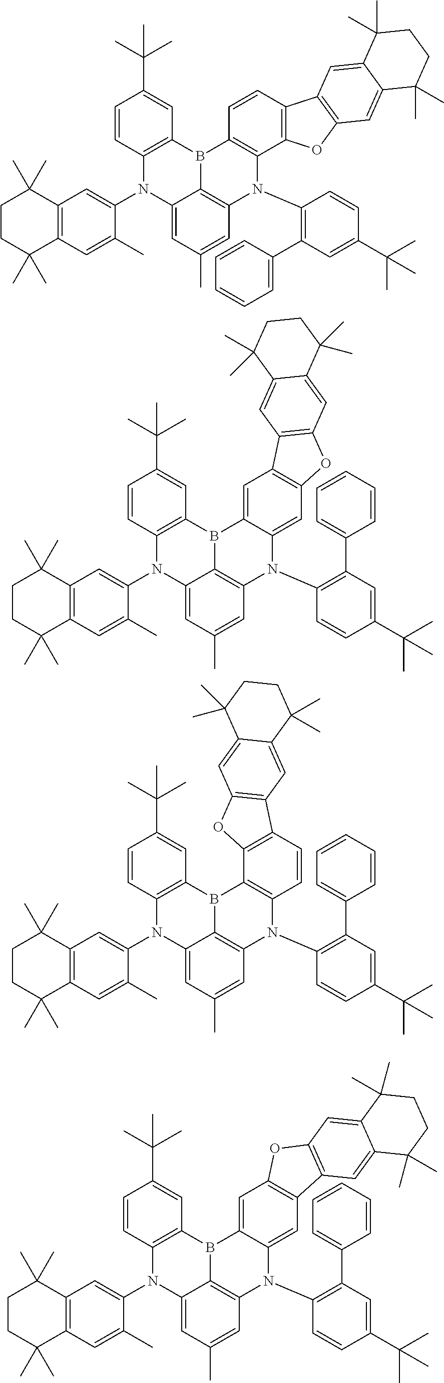

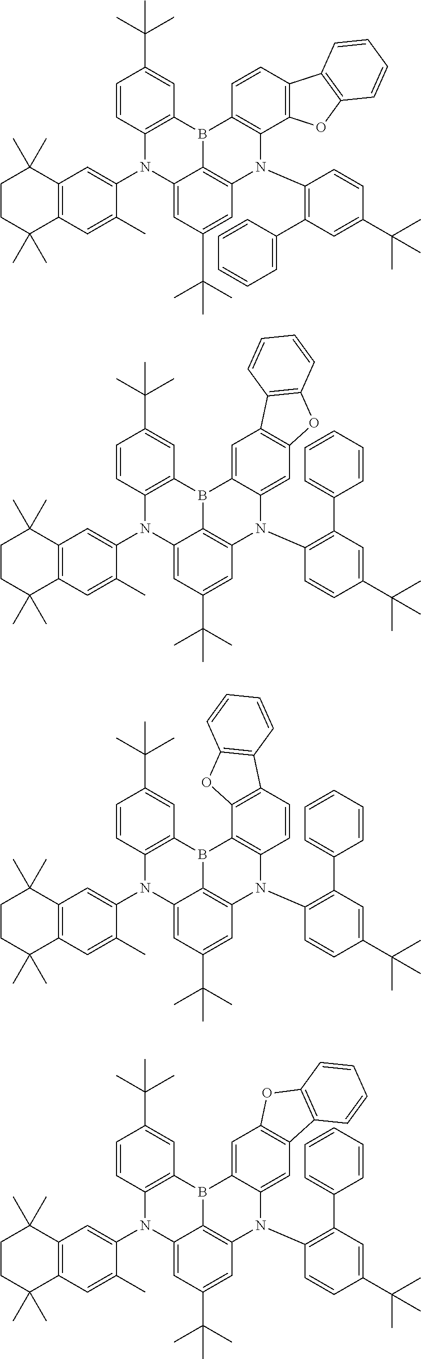

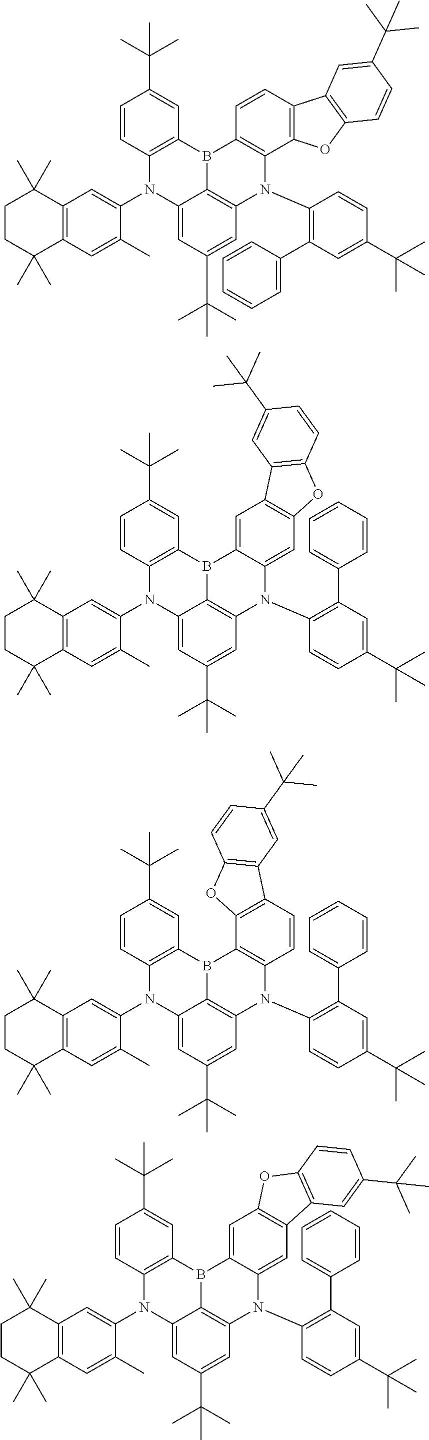

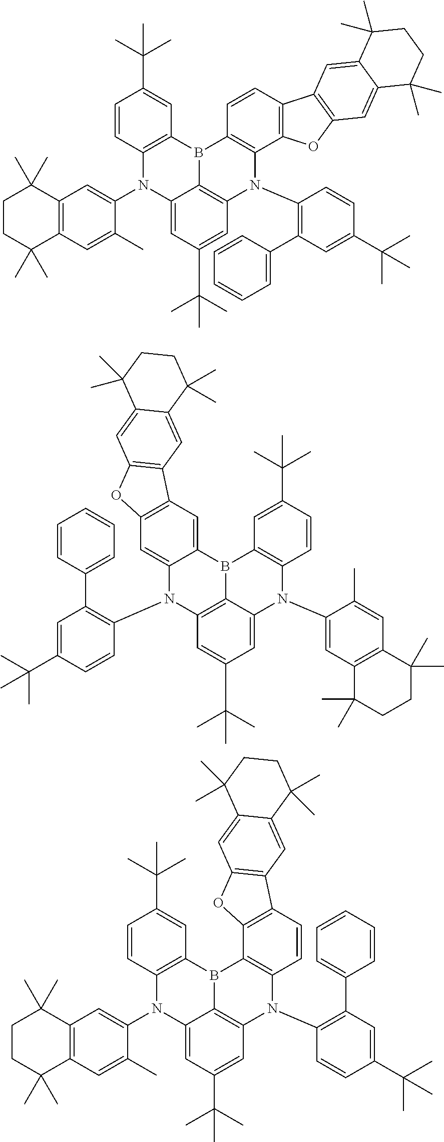

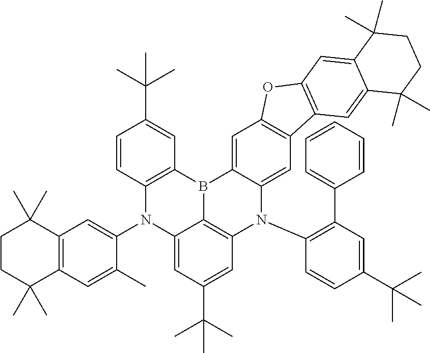 [SMILES: Cc1cc2c(cc1N1c3ccc(C(C)(C)C)cc3B3c4cc5oc6cc7c(cc6c5cc4N(c4ccc(C(C)(C)C)cc4-c4ccccc4)c4cc(C(C)(C)C)cc1c43)C(C)(C)CCC7(C)C)C(C)(C)CCC2(C)C]

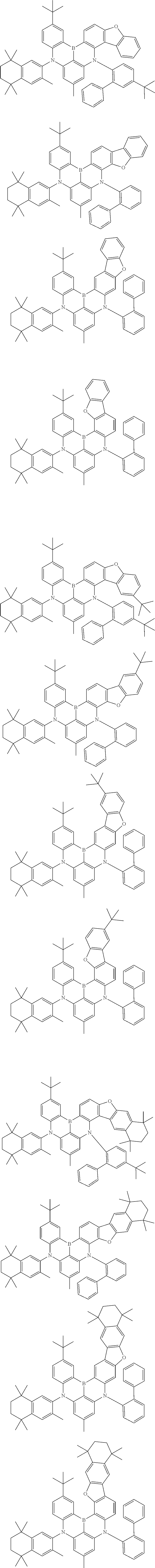

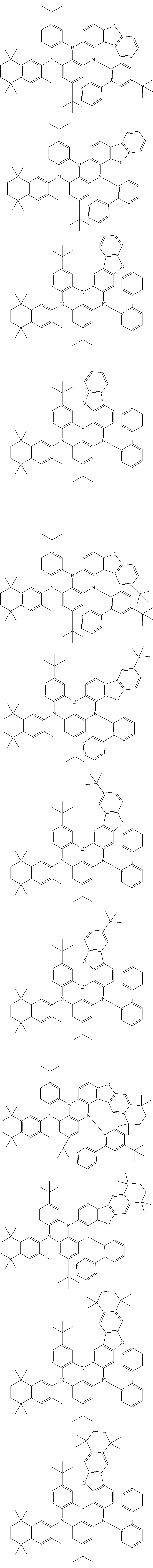

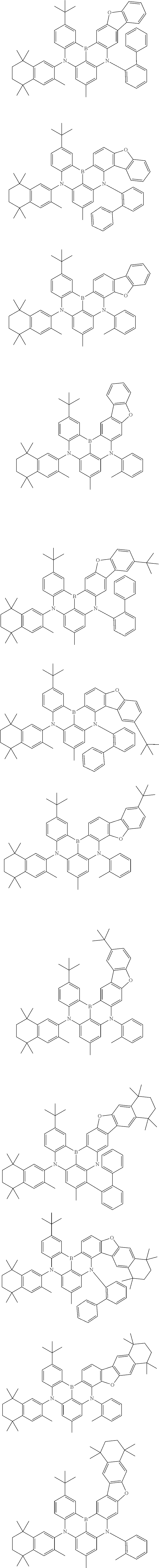

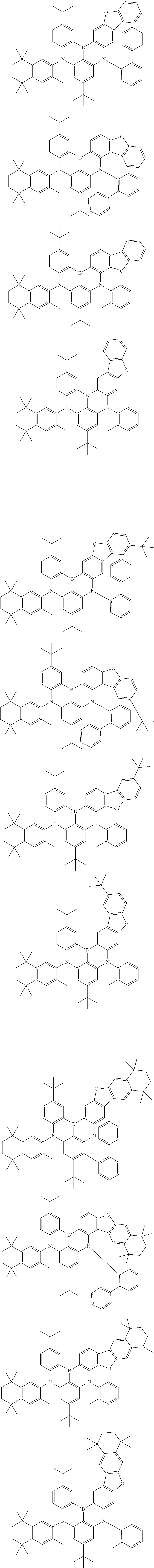

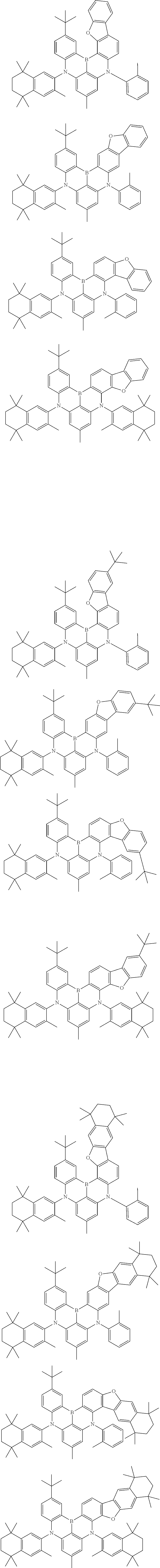

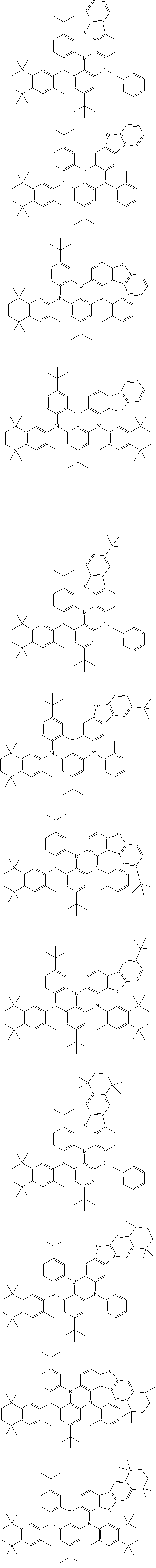

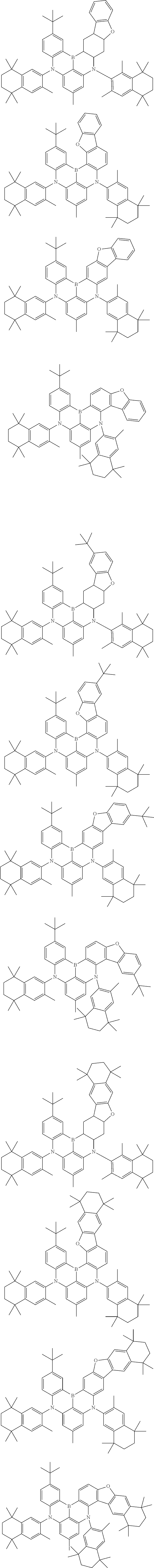

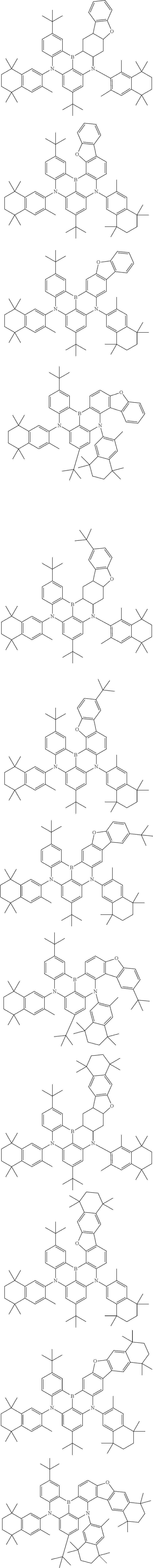

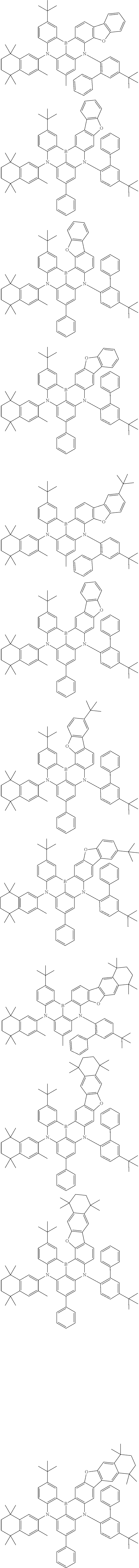

[chemical structure]

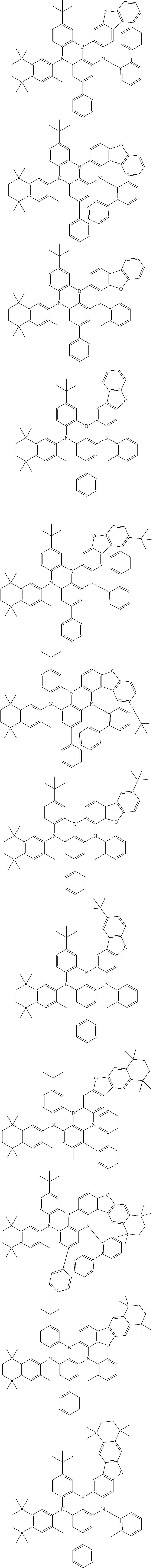

[chemical structure]

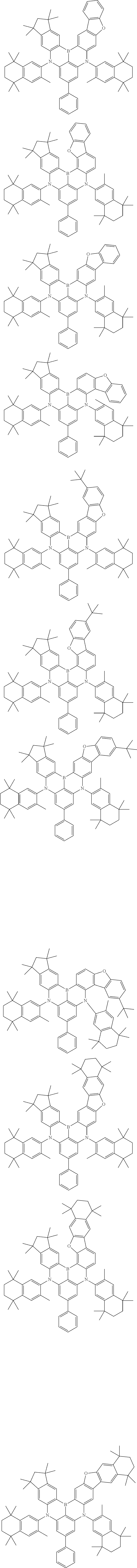

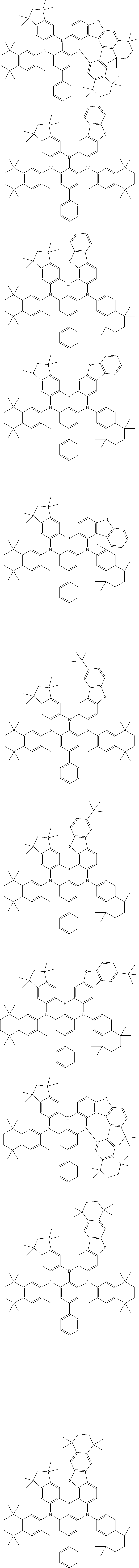

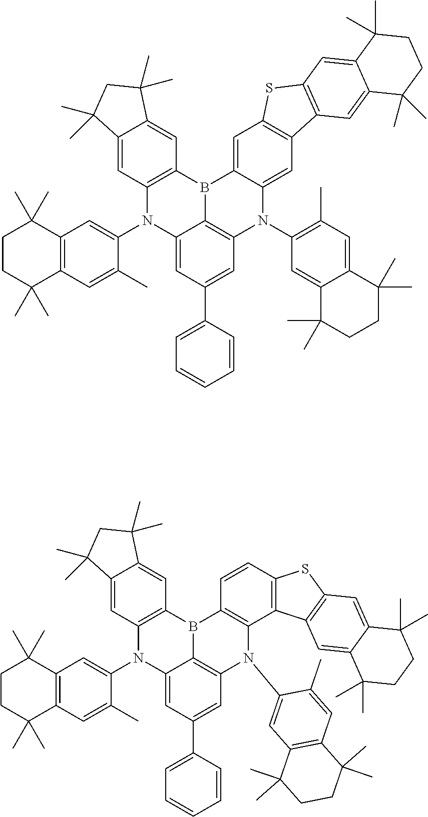 [SMILES: Cc1cc2c(cc1N1c3cc4c(cc3B3c5cc6sc7cc8c(cc7c6cc5N(c5cc6c(cc5C)C(C)(C)CCC6(C)C)c5cc(-c6ccccc6)cc1c53)C(C)(C)CCC8(C)C)C(C)(C)CC4(C)C)C(C)(C)CCC2(C)C ; Cc1cc2c(cc1N1c3cc4c(cc3B3c5ccc6sc7cc8c(cc7c6c5N(c5cc6c(cc5C)C(C)(C)CCC6(C)C)c5cc(-c6ccccc6)cc1c53)C(C)(C)CCC8(C)C)C(C)(C)CC4(C)C)C(C)(C)CCC2(C)C]

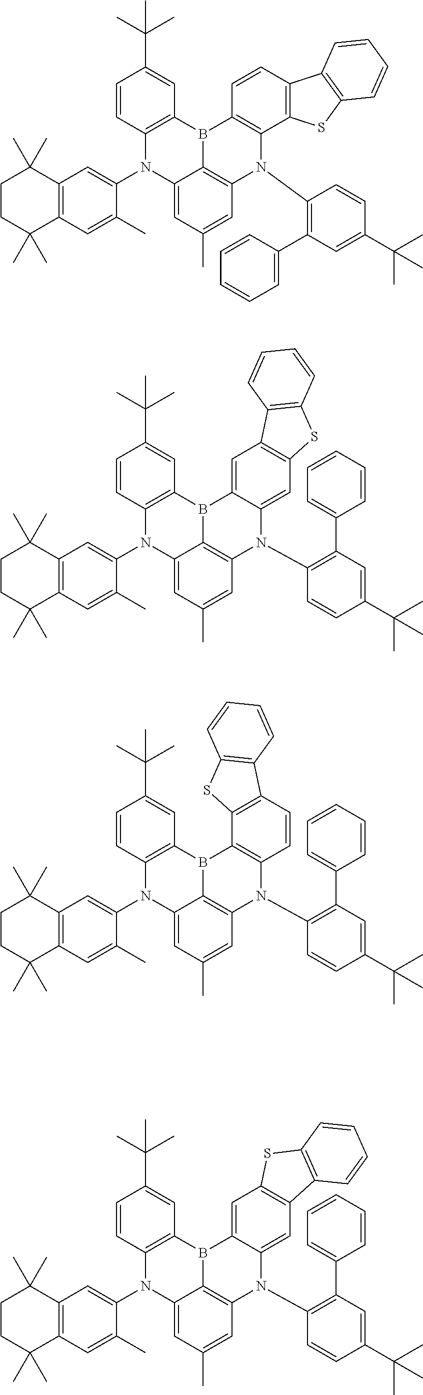 [SMILES: Cc1cc2c3c(c1)N(c1ccc(C(C)(C)C)cc1-c1ccccc1)c1c(ccc4c1sc1ccccc14)B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1cc4sc5ccccc5c4cc1B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1ccc4c(sc5ccccc54)c1B3c1cc(C(C)(C)C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)sc1ccccc14]

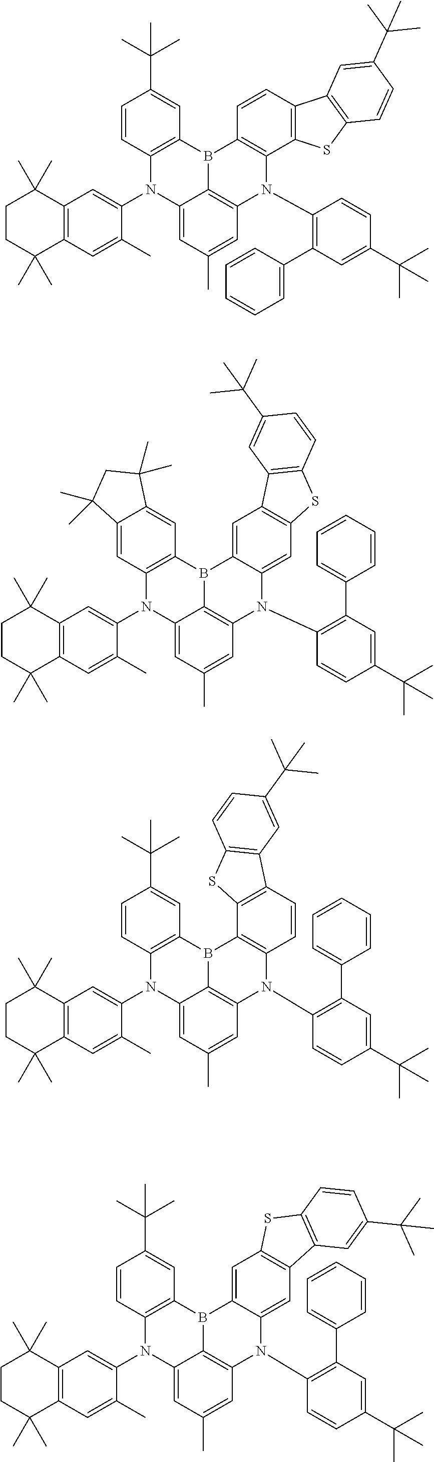

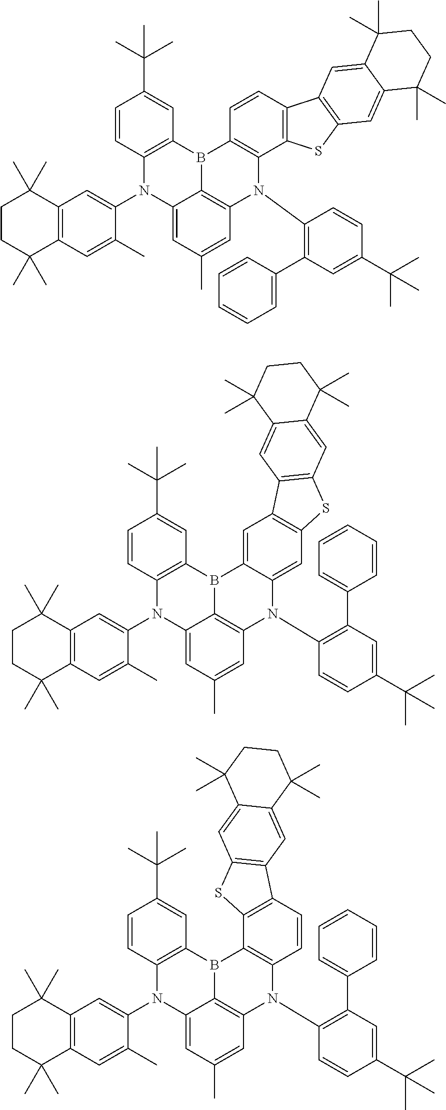

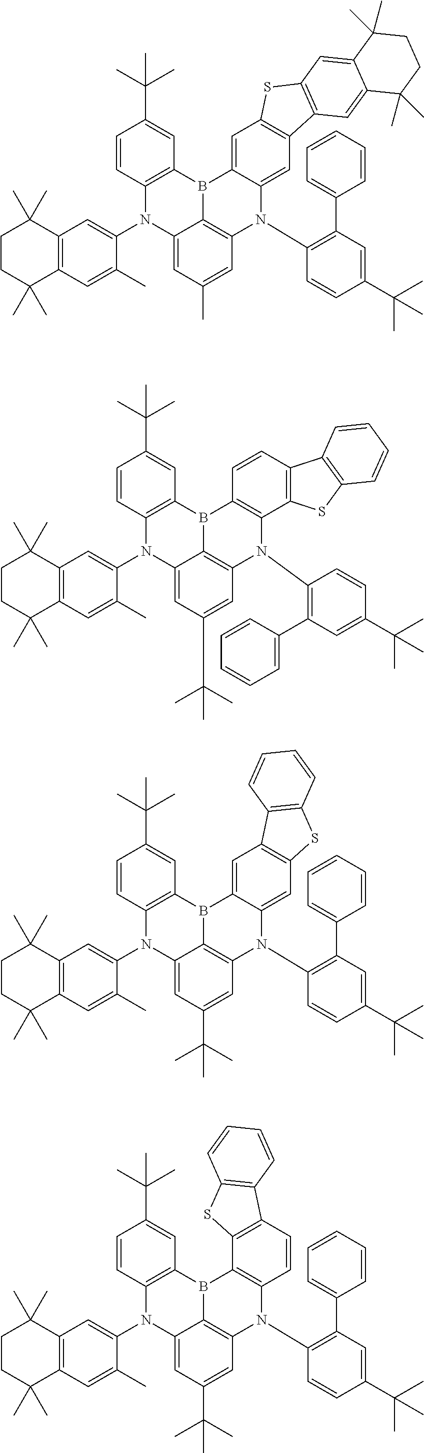 [SMILES: Cc1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1cc2c(cc1N1c3ccc(C(C)(C)C)cc3B3c4ccc5c(sc6ccccc65)c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(C(C)(C)C)cc1c43)sc1ccccc15)C(C)(C)CCC2(C)C ; Cc1cc2c(cc1N1c3ccc(C(C)(C)C)cc3B3c4c1cc(C(C)(C)C)cc4N(c1ccc(C(C)(C)C)cc1-c1ccccc1)c1ccc4c(sc5ccccc54)c13)C(C)(C)CCC2(C)C]

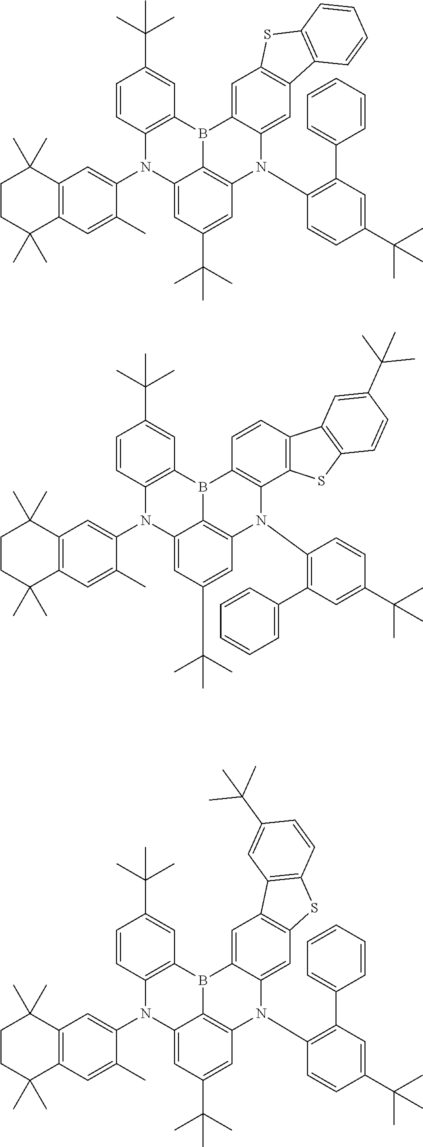 [SMILES: Cc1cc2c(cc1N1c3ccc(C(C)(C)C)cc3B3c4cc5sc6ccccc6c5cc4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(C(C)(C)C)cc1c43)sc1ccc(C(C)(C)C)cc15)C(C)(C)CCC2(C)C]

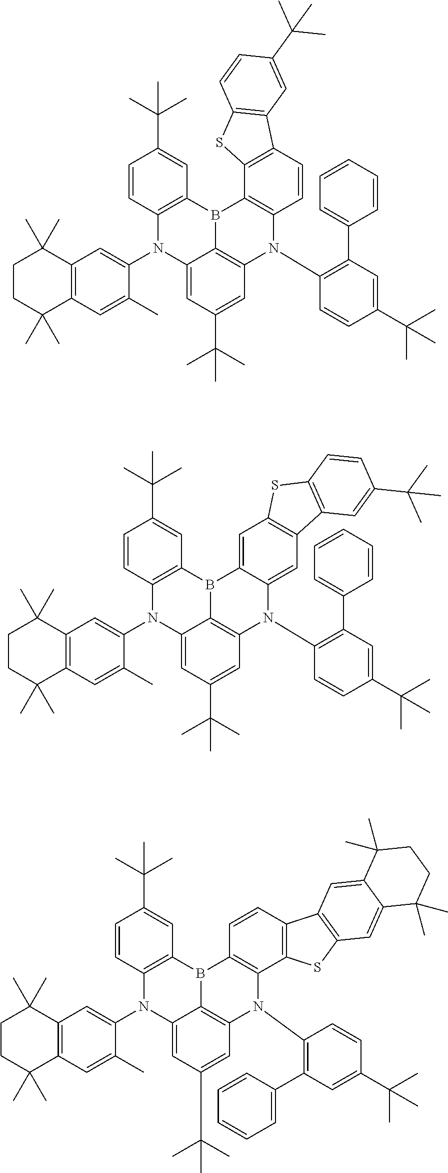 [SMILES: Cc1cc2c(cc1N1c3ccc(C(C)(C)C)cc3B3c4c1cc(C(C)(C)C)cc4N(c1ccc(C(C)(C)C)cc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4cc5sc6ccc(C(C)(C)C)cc6c5cc4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccc(C(C)(C)C)cc4-c4ccccc4)c4cc(C(C)(C)C)cc1c43)C(C)(C)CCC2(C)C]

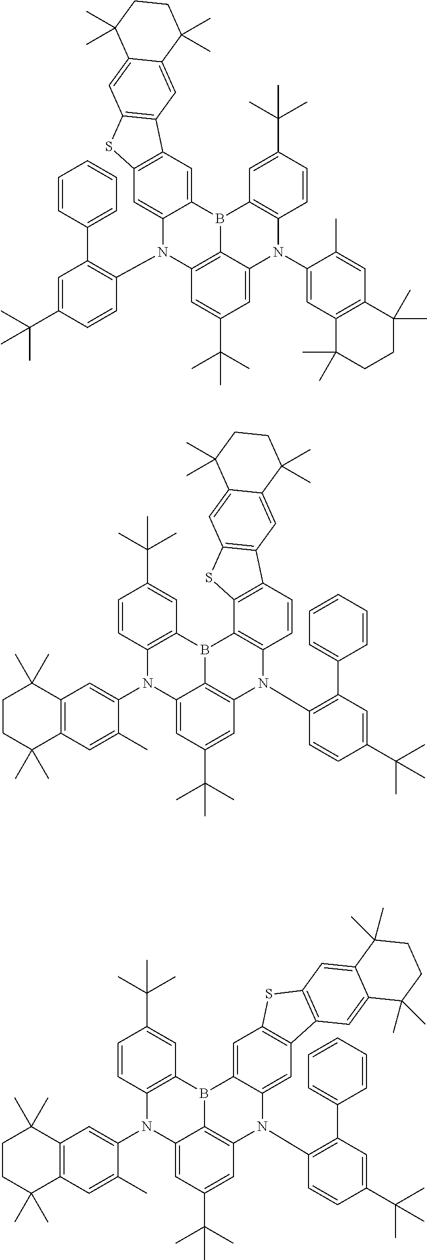 [SMILES: Cc1cc2c(cc1N1c3ccc(C(C)(C)C)cc3B3c4cc5c(cc4N(c4ccc(C(C)(C)C)cc4-c4ccccc4)c4cc(C(C)(C)C)cc1c43)sc1cc3c(cc15)C(C)(C)CCC3(C)C)C(C)(C)CCC2(C)C ; Cc1cc2c(cc1N1c3ccc(C(C)(C)C)cc3B3c4c1cc(C(C)(C)C)cc4N(c1ccc(C(C)(C)C)cc1-c1ccccc1)c1ccc4c(sc5cc6c(cc54)C(C)(C)CCC6(C)C)c13)C(C)(C)CCC2(C)C ; Cc1cc2c(cc1N1c3ccc(C(C)(C)C)cc3B3c4cc5sc6cc7c(cc6c5cc4N(c4ccc(C(C)(C)C)cc4-c4ccccc4)c4cc(C(C)(C)C)cc1c43)C(C)(C)CCC7(C)C)C(C)(C)CCC2(C)C]

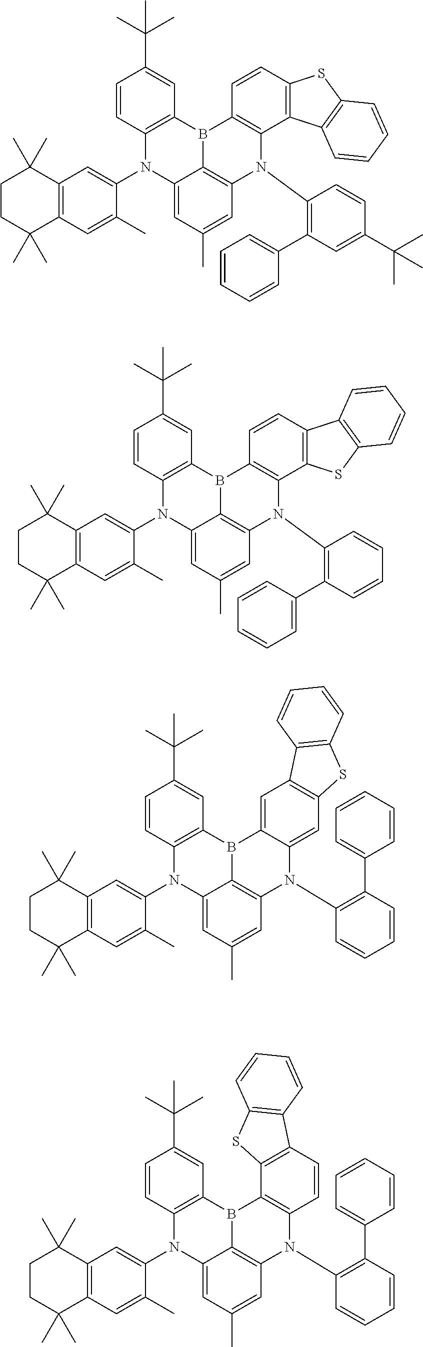 [SMILES: Cc1cc2c3c(c1)N(c1ccc(C(C)(C)C)cc1-c1ccccc1)c1c(ccc4sc5ccccc5c14)B3c1cc(C(C)(C)C)ccc1N2c1cc2c(cc1C)C(C)(C)CCC2(C)C ; Cc1cc2c3c(c1)N(c1ccccc1-c1ccccc1)c1c(ccc4c1sc1ccccc14)B3c1cc(C(C)(C)C)ccc1N2c1cc2c(cc1C)C(C)(C)CCC2(C)C ; Cc1cc2c3c(c1)N(c1ccccc1-c1ccccc1)c1cc4sc5ccccc5c4cc1B3c1cc(C(C)(C)C)ccc1N2c1cc2c(cc1C)C(C)(C)CCC2(C)C ; Cc1cc2c3c(c1)N(c1ccccc1-c1ccccc1)c1ccc4c(sc5ccccc54)c1B3c1cc(C(C)(C)C)ccc1N2c1cc2c(cc1C)C(C)(C)CCC2(C)C]

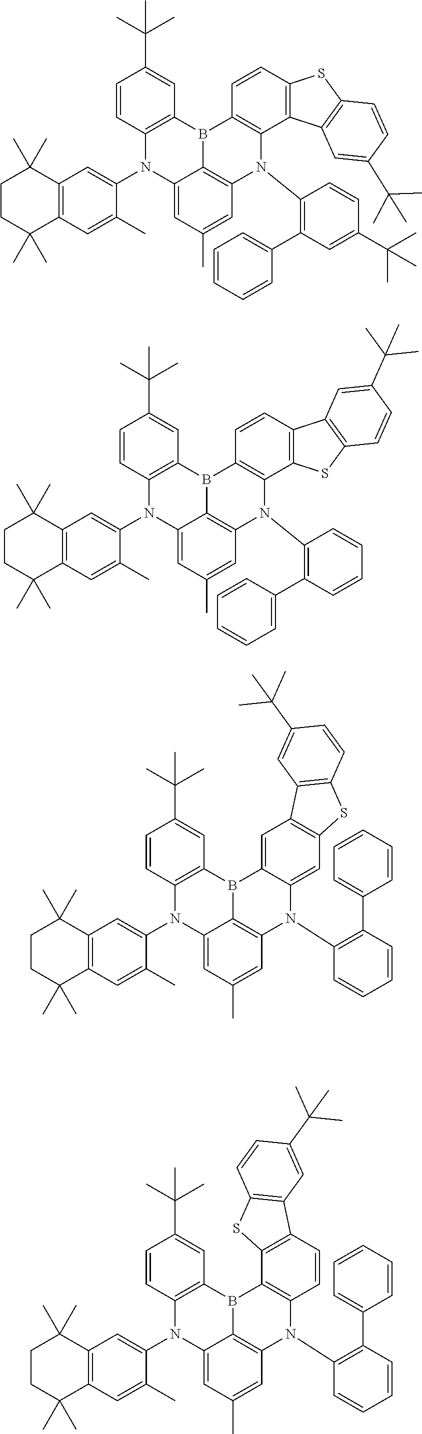

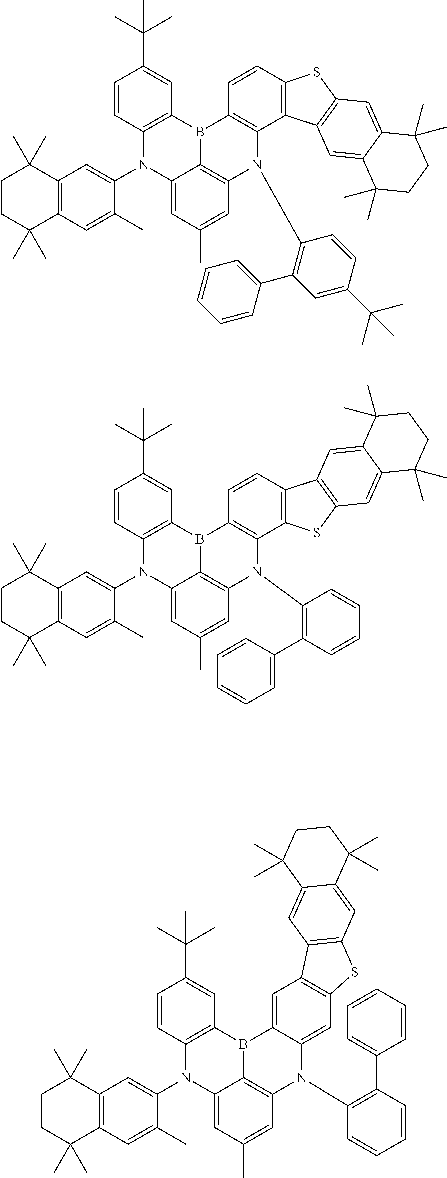

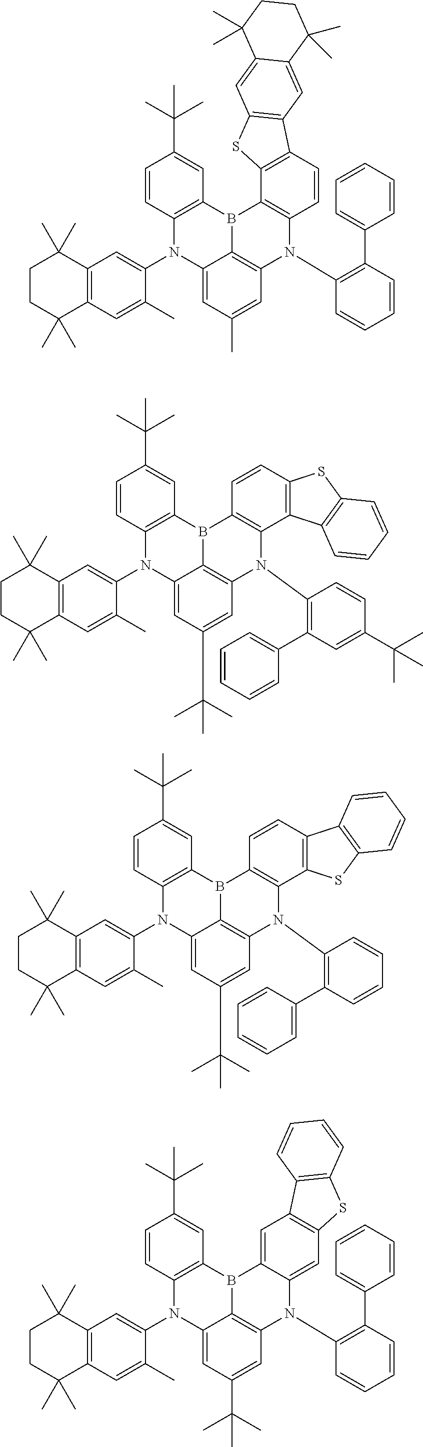

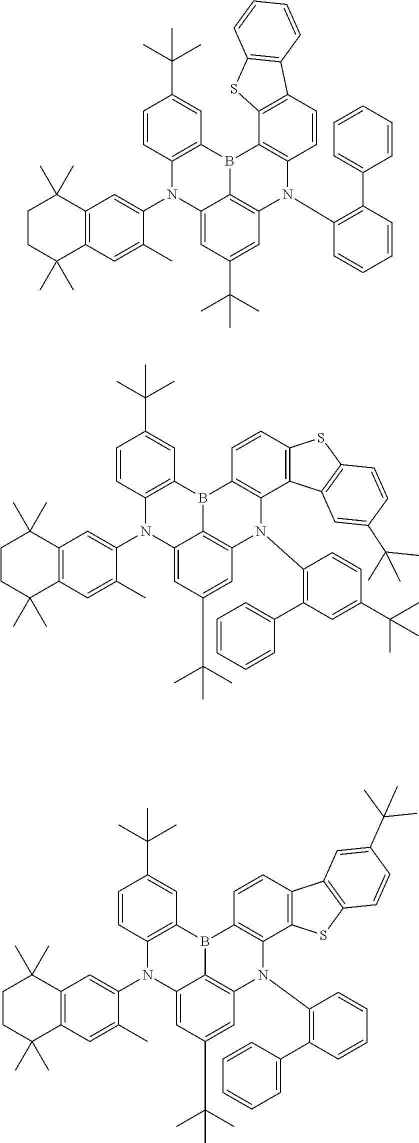 [SMILES: Cc1cc2c(cc1N1c3ccc(C(C)(C)C)cc3B3c4c1cc(C(C)(C)C)cc4N(c1ccccc1-c1ccccc1)c1ccc4c(sc5ccccc54)c13)C(C)(C)CCC2(C)C ; Cc1cc2c(cc1N1c3ccc(C(C)(C)C)cc3B3c4ccc5sc6ccc(C(C)(C)C)cc6c5c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4-c4ccccc4)c4cc(C(C)(C)C)cc1c43)C(C)(C)CCC2(C)C]

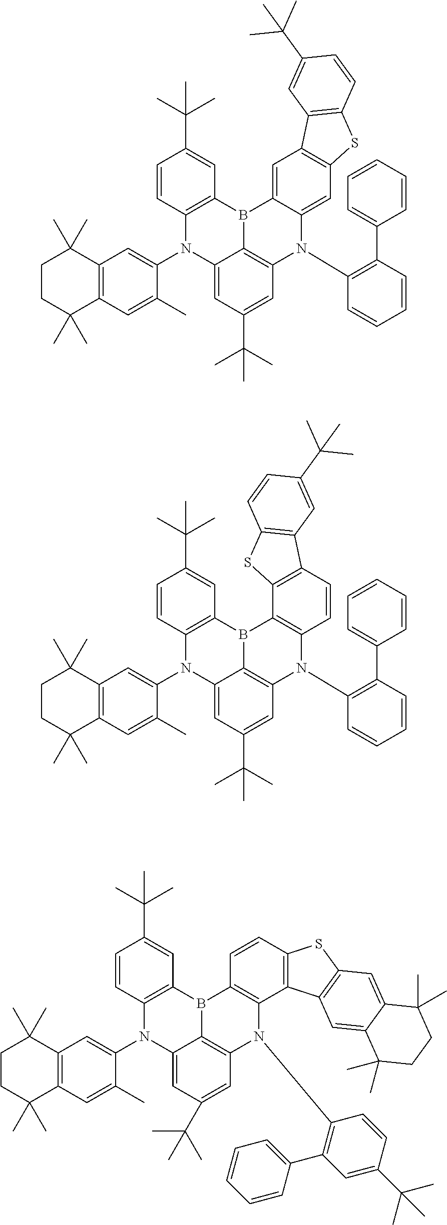 [SMILES: Cc1cc2c(cc1N1c3ccc(C(C)(C)C)cc3B3c4cc5c(cc4N(c4ccccc4-c4ccccc4)c4cc(C(C)(C)C)cc1c43)sc1ccc(C(C)(C)C)cc15)C(C)(C)CCC2(C)C ; Cc1cc2c(cc1N1c3ccc(C(C)(C)C)cc3B3c4c1cc(C(C)(C)C)cc4N(c1ccccc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4ccc5sc6cc7c(cc6c5c4N(c4ccc(C(C)(C)C)cc4-c4ccccc4)c4cc(C(C)(C)C)cc1c43)C(C)(C)CCC7(C)C)C(C)(C)CCC2(C)C]

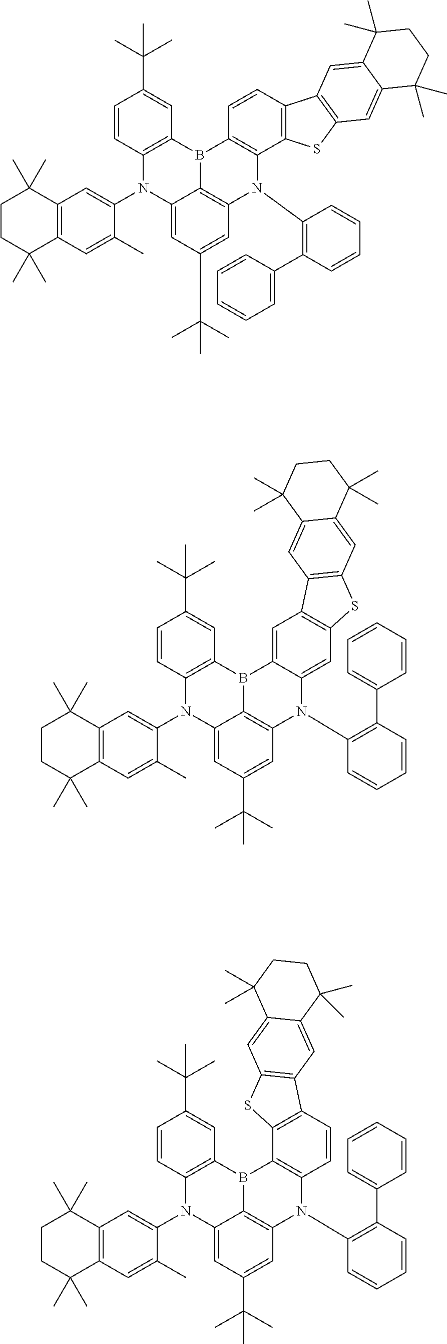 [SMILES: Cc1cc2c(cc1N1c3ccc(C(C)(C)C)cc3B3c4ccc5c(sc6cc7c(cc65)C(C)(C)CCC7(C)C)c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(C(C)(C)C)cc1c43)sc1cc3c(cc15)C(C)(C)CCC3(C)C)C(C)(C)CCC2(C)C ; Cc1cc2c(cc1N1c3ccc(C(C)(C)C)cc3B3c4c1cc(C(C)(C)C)cc4N(c1ccccc1-c1ccccc1)c1ccc4c(sc5cc6c(cc54)C(C)(C)CCC6(C)C)c13)C(C)(C)CCC2(C)C]

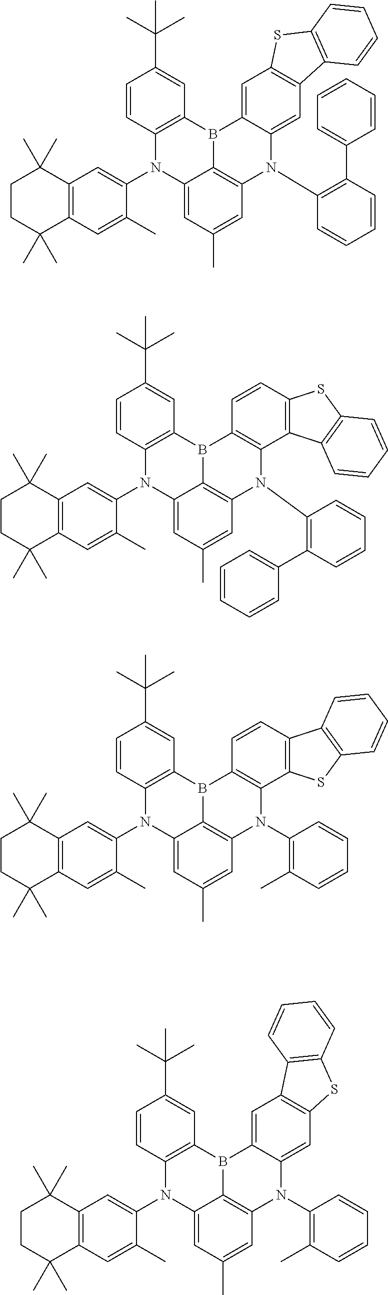 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1ccccc14 ; Cc1cc2c3c(c1)N(c1ccccc1-c1ccccc1)c1c(ccc4sc5ccccc5c14)B3c1cc(C(C)(C)C)ccc1N2c1cc2c(cc1C)C(C)(C)CCC2(C)C ; Cc1cc2c3c(c1)N(c1ccccc1C)c1c(ccc4c1sc1ccccc14)B3c1cc(C(C)(C)C)ccc1N2c1cc2c(cc1C)C(C)(C)CCC2(C)C ; Cc1cc2c3c(c1)N(c1ccccc1C)c1cc4sc5ccccc5c4cc1B3c1cc(C(C)(C)C)ccc1N2c1cc2c(cc1C)C(C)(C)CCC2(C)C]

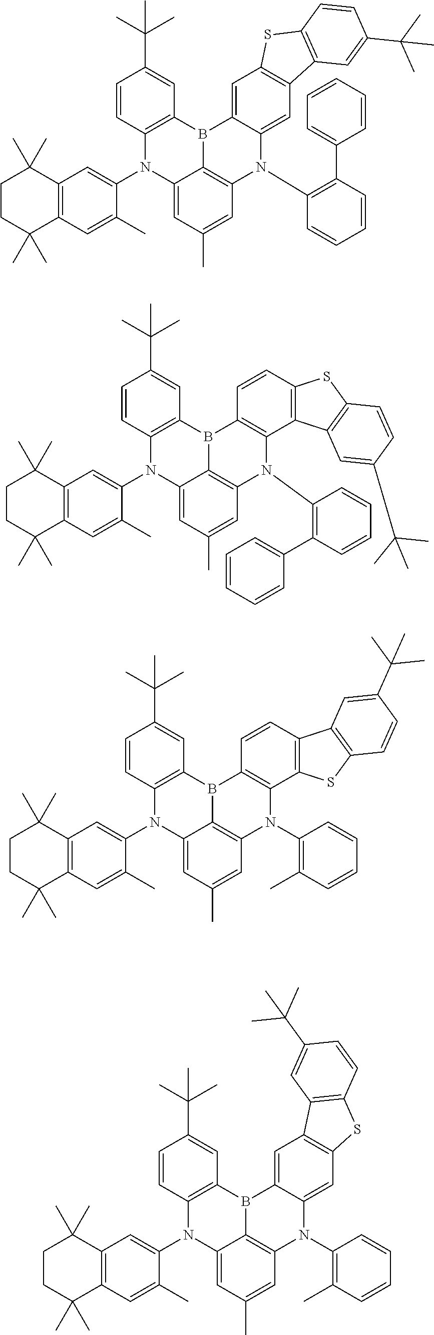 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1ccc(C(C)(C)C)cc14 ; Cc1cc2c3c(c1)N(c1ccccc1-c1ccccc1)c1c(ccc4sc5ccc(C(C)(C)C)cc5c14)B3c1cc(C(C)(C)C)ccc1N2c1cc2c(cc1C)C(C)(C)CCC2(C)C ; Cc1cc2c3c(c1)N(c1ccccc1C)c1c(ccc4c1sc1ccc(C(C)(C)C)cc14)B3c1cc(C(C)(C)C)ccc1N2c1cc2c(cc1C)C(C)(C)CCC2(C)C ; Cc1cc2c3c(c1)N(c1ccccc1C)c1cc4sc5ccc(C(C)(C)C)cc5c4cc1B3c1cc(C(C)(C)C)ccc1N2c1cc2c(cc1C)C(C)(C)CCC2(C)C]

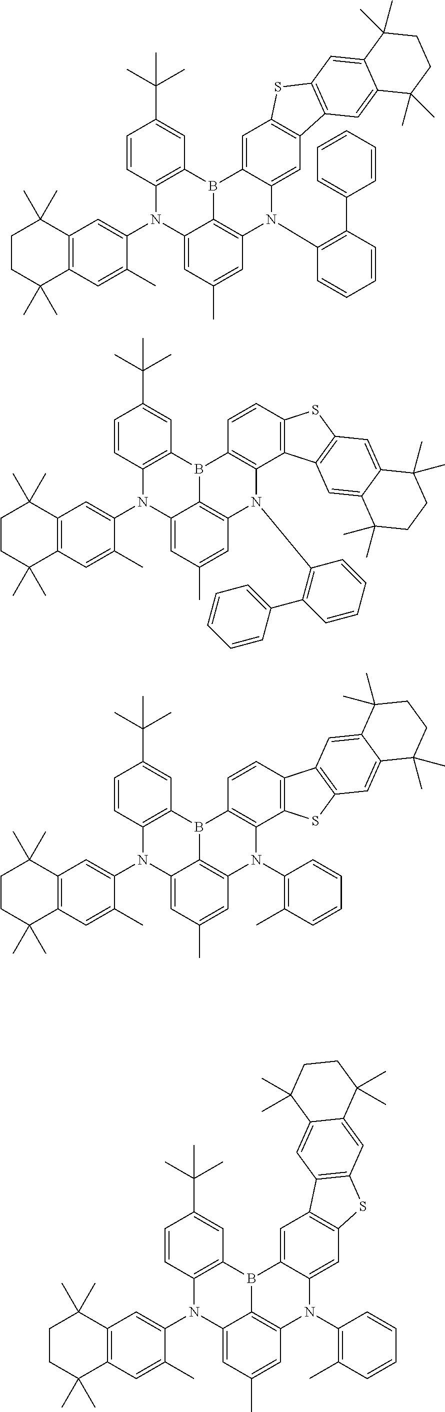 [SMILES: Cc1cc2c3c(c1)N(c1ccccc1-c1ccccc1)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1cc2c3c(c1)N(c1ccccc1-c1ccccc1)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1cc2c3c(c1)N(c1ccccc1C)c1c(ccc4c1sc1cc5c(cc14)C(C)(C)CCC5(C)C)B3c1cc(C(C)(C)C)ccc1N2c1cc2c(cc1C)C(C)(C)CCC2(C)C ; Cc1cc2c3c(c1)N(c1ccccc1C)c1cc4sc5cc6c(cc5c4cc1B3c1cc(C(C)(C)C)ccc1N2c1cc2c(cc1C)C(C)(C)CCC2(C)C)C(C)(C)CCC6(C)C]

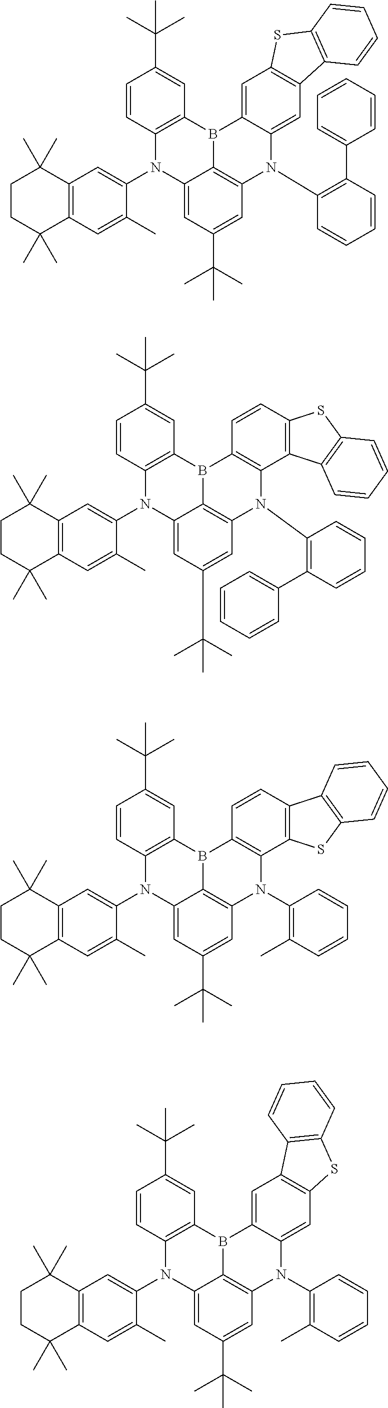 [SMILES: Cc1cc2c(cc1N1c3ccc(C(C)(C)C)cc3B3c4cc5sc6ccccc6c5cc4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5sc6ccccc6c5c4N(c4ccccc4-c4ccccc4)c4cc(C(C)(C)C)cc1c43)C(C)(C)CCC2(C)C ; Cc1cc2c(cc1N1c3ccc(C(C)(C)C)cc3B3c4ccc5c(sc6ccccc65)c4N(c4ccccc4C)c4cc(C(C)(C)C)cc1c43)C(C)(C)CCC2(C)C ; Cc1ccccc1N1c2cc3sc4ccccc4c3cc2B2c3cc(C(C)(C)C)ccc3N(c3cc4c(cc3C)C(C)(C)CCC4(C)C)c3cc(C(C)(C)C)cc1c32]

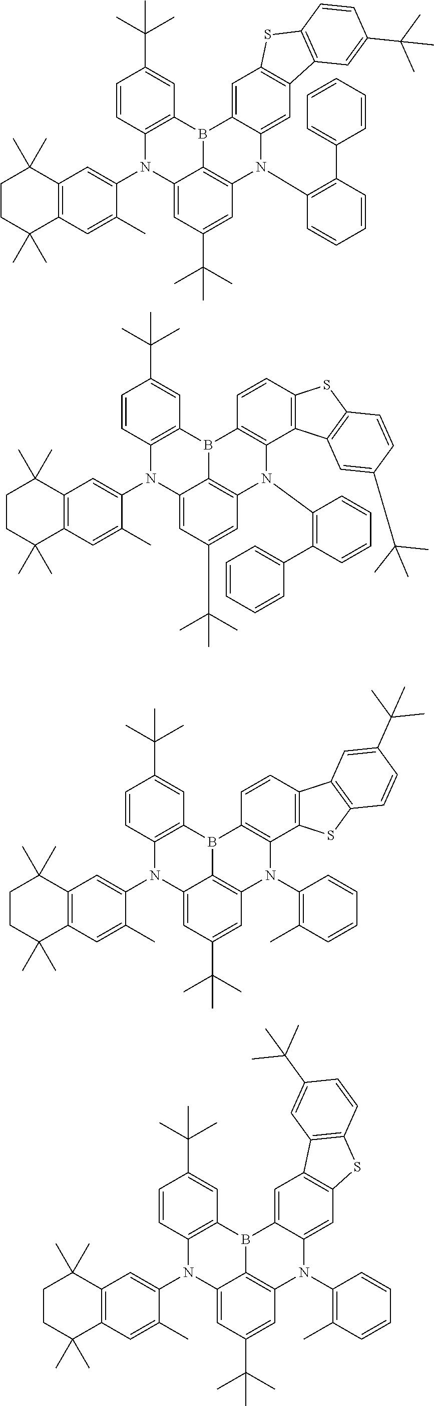

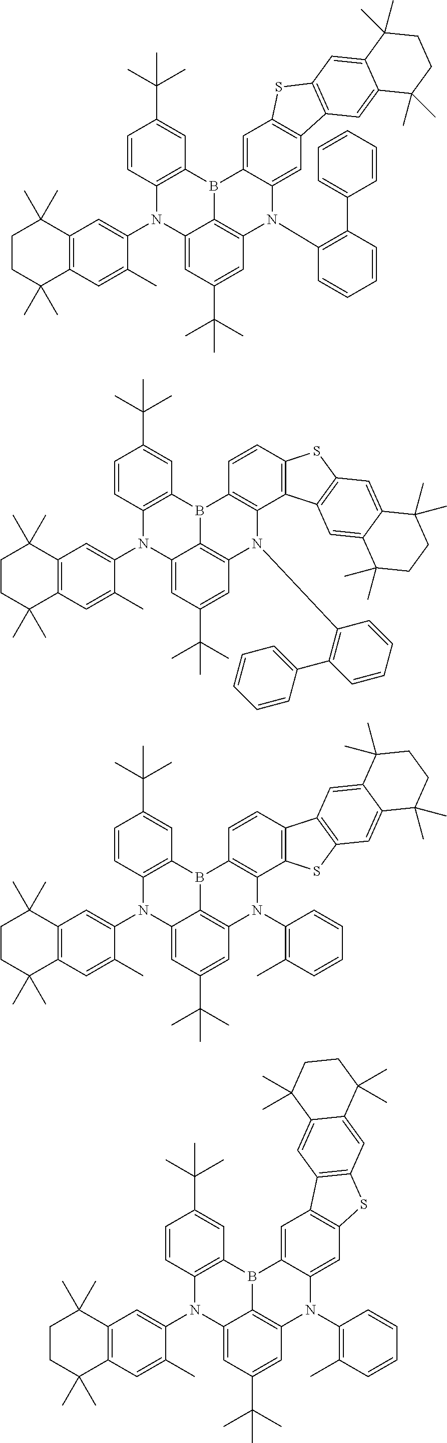

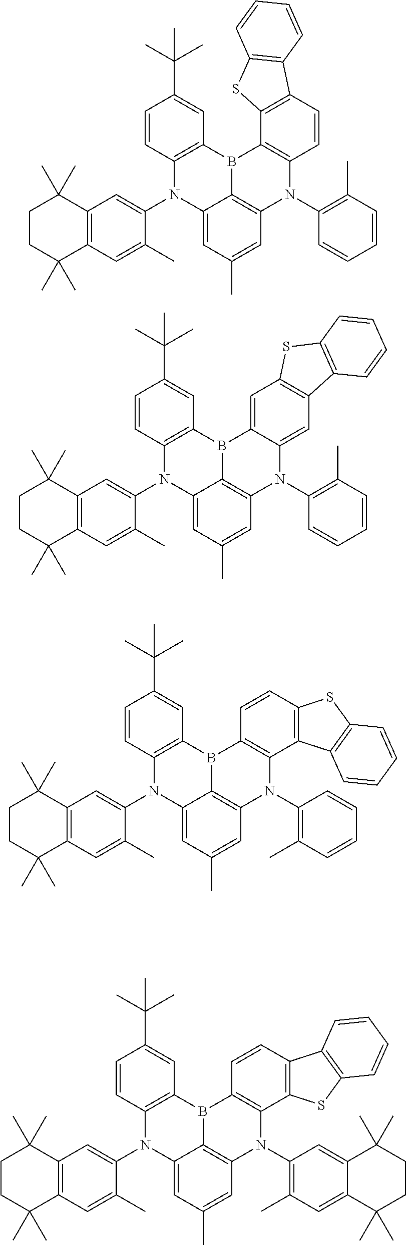 [SMILES: Cc1cc2c3c(c1)N(c1ccccc1C)c1ccc4c(sc5ccccc54)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)sc1ccccc14 ; Cc1cc2c3c(c1)N(c1ccccc1C)c1c(ccc4sc5ccccc5c14)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1sc1ccccc14)B3c1cc(C(C)(C)C)ccc1N2c1cc2c(cc1C)C(C)(C)CCC2(C)C]

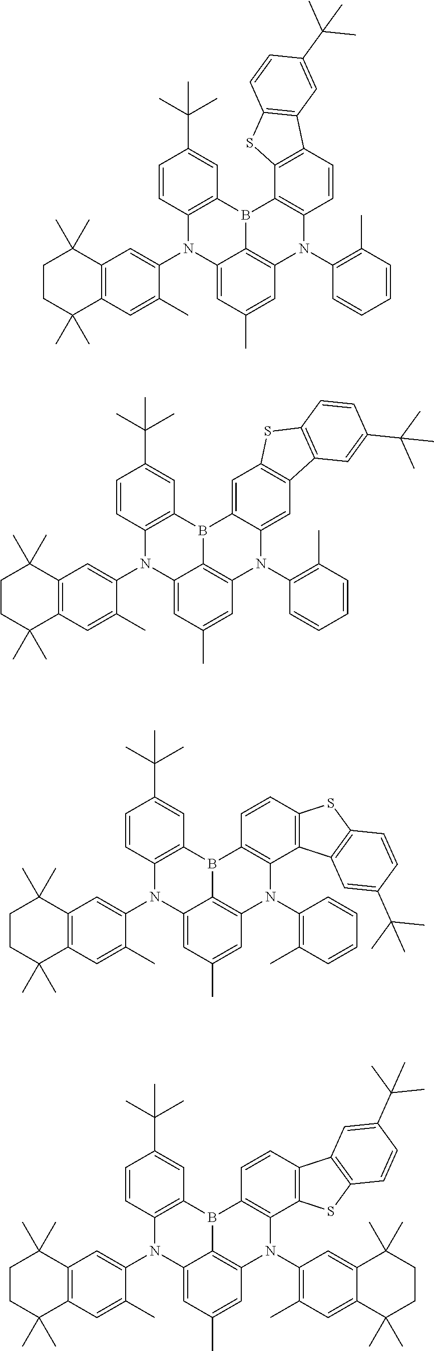 [SMILES: Cc1cc2c3c(c1)N(c1ccccc1C)c1ccc4c(sc5ccc(C(C)(C)C)cc54)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)sc1ccc(C(C)(C)C)cc14 ; Cc1cc2c3c(c1)N(c1ccccc1C)c1c(ccc4sc5ccc(C(C)(C)C)cc5c14)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1sc1ccc(C(C)(C)C)cc14)B3c1cc(C(C)(C)C)ccc1N2c1cc2c(cc1C)C(C)(C)CCC2(C)C]

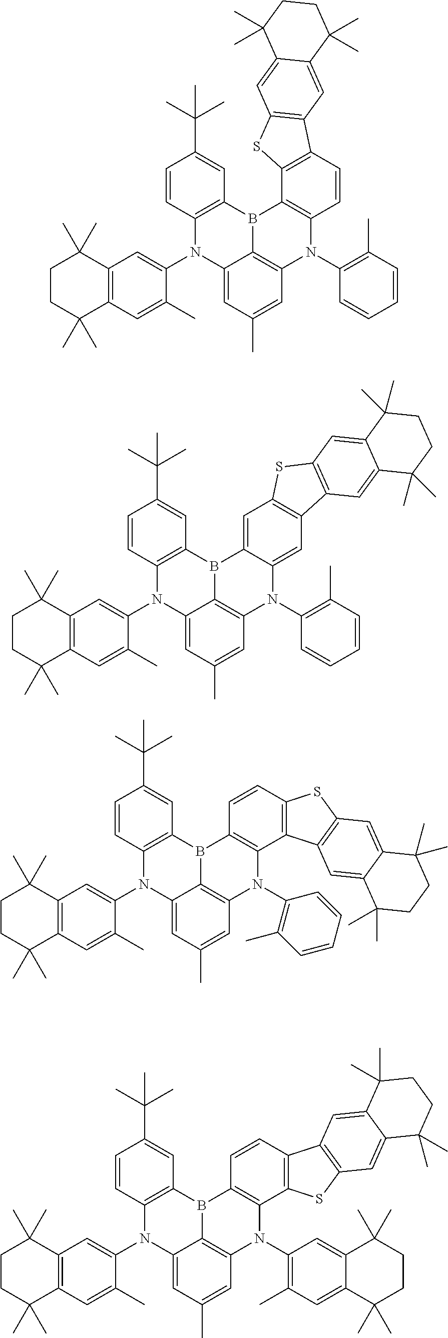 [SMILES: Cc1cc2c3c(c1)N(c1ccccc1C)c1ccc4c(sc5cc6c(cc54)C(C)(C)CCC6(C)C)c1B3c1cc(C(C)(C)C)ccc1N2c1cc2c(cc1C)C(C)(C)CCC2(C)C ; Cc1cc2c3c(c1)N(c1ccccc1C)c1cc4c(cc1B3c1cc(C(C)(C)C)ccc1N2c1cc2c(cc1C)C(C)(C)CCC2(C)C)sc1cc2c(cc14)C(C)(C)CCC2(C)C ; Cc1cc2c3c(c1)N(c1ccccc1C)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1c(ccc4c1sc1cc5c(cc14)C(C)(C)CCC5(C)C)B3c1cc(C(C)(C)C)ccc1N2c1cc2c(cc1C)C(C)(C)CCC2(C)C]

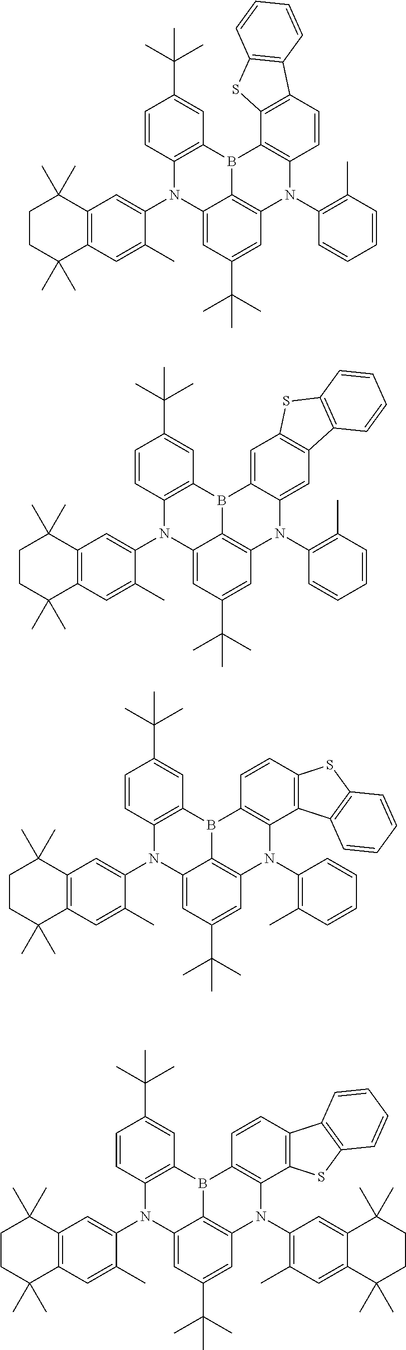 [SMILES: Cc1cc2c(cc1N1c3ccc(C(C)(C)C)cc3B3c4c1cc(C(C)(C)C)cc4N(c1ccccc1C)c1ccc4c(sc5ccccc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(C(C)(C)C)cc1c42)sc1ccccc13 ; Cc1cc2c(cc1N1c3ccc(C(C)(C)C)cc3B3c4ccc5sc6ccccc6c5c4N(c4ccccc4C)c4cc(C(C)(C)C)cc1c43)C(C)(C)CCC2(C)C ; Cc1cc2c(cc1N1c3ccc(C(C)(C)C)cc3B3c4ccc5c(sc6ccccc65)c4N(c4cc5c(cc4C)C(C)(C)CCC5(C)C)c4cc(C(C)(C)C)cc1c43)C(C)(C)CCC2(C)C]

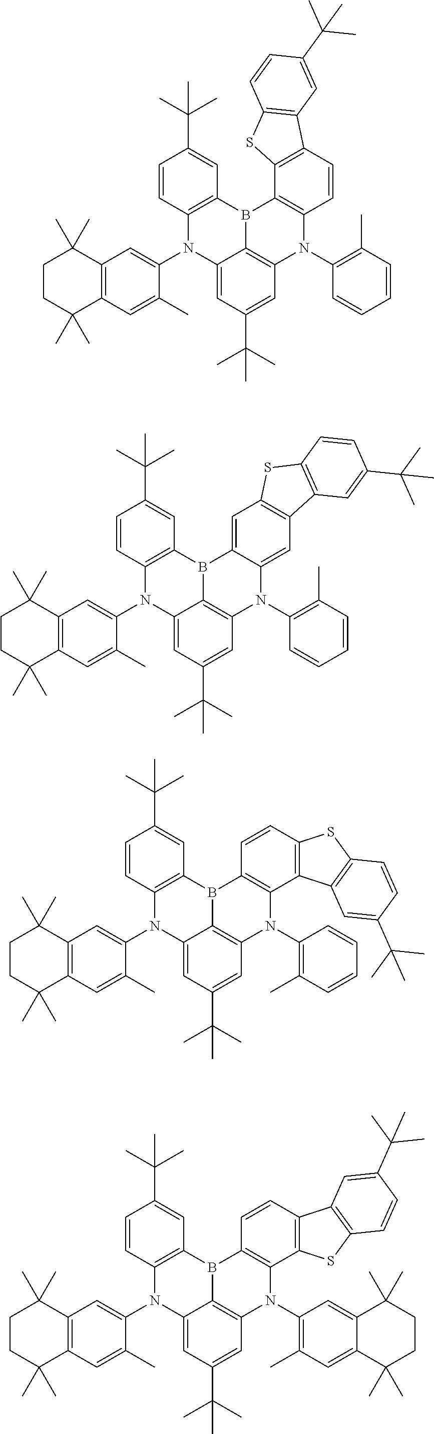

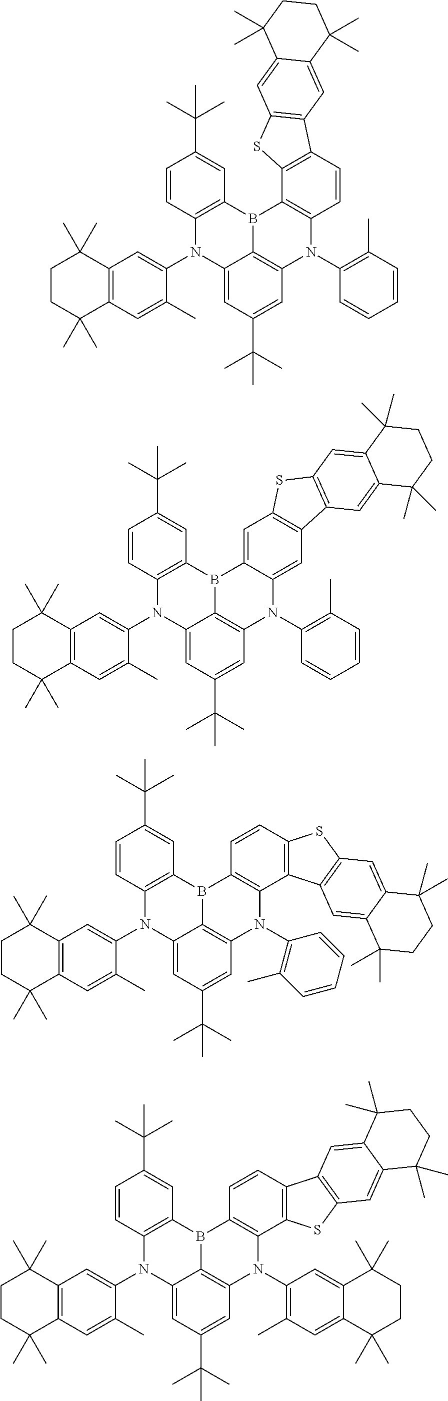

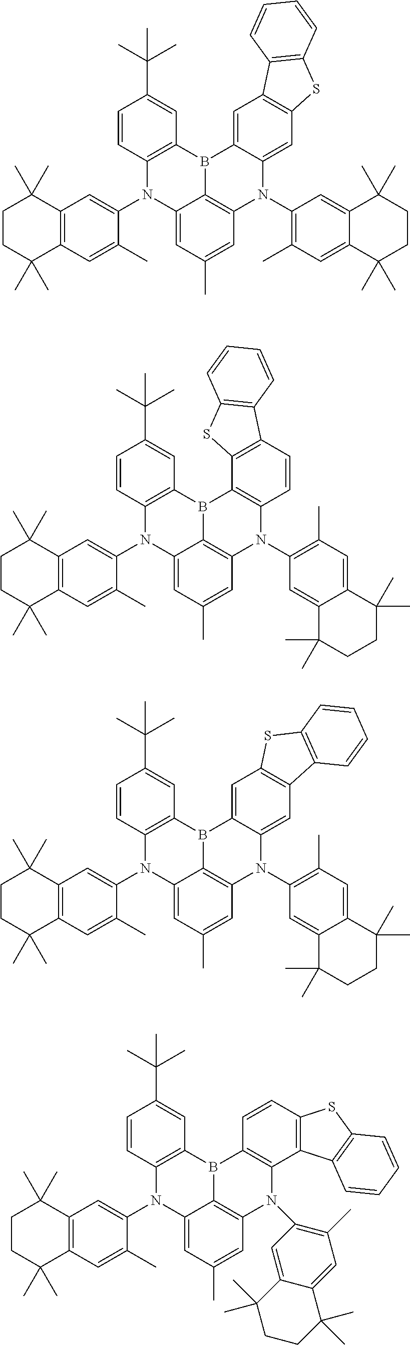

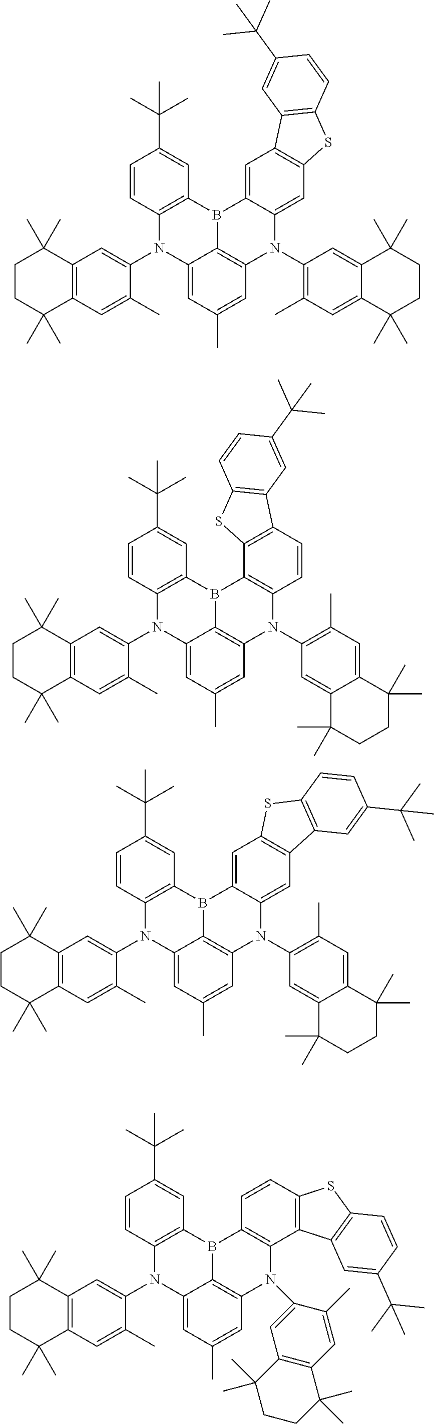

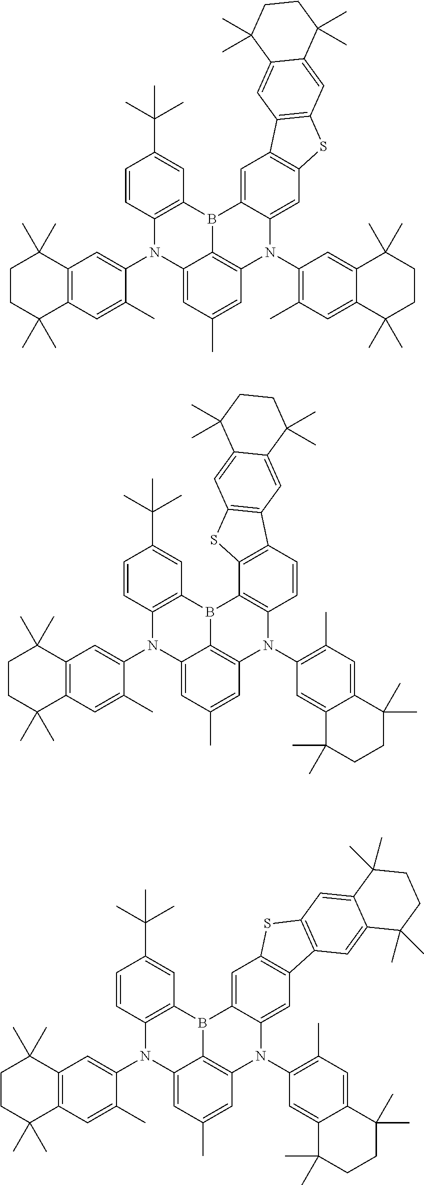 [SMILES: Cc1cc2c3c(c1)N(c1cc4c(cc1C)C(C)(C)CCC4(C)C)c1cc4sc5cc6c(cc5c4cc1B3c1cc(C(C)(C)C)ccc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(sc5cc6c(cc54)C(C)(C)CCC6(C)C)c1B3c1cc(C(C)(C)C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)sc1cc2c(cc14)C(C)(C)CCC2(C)C]

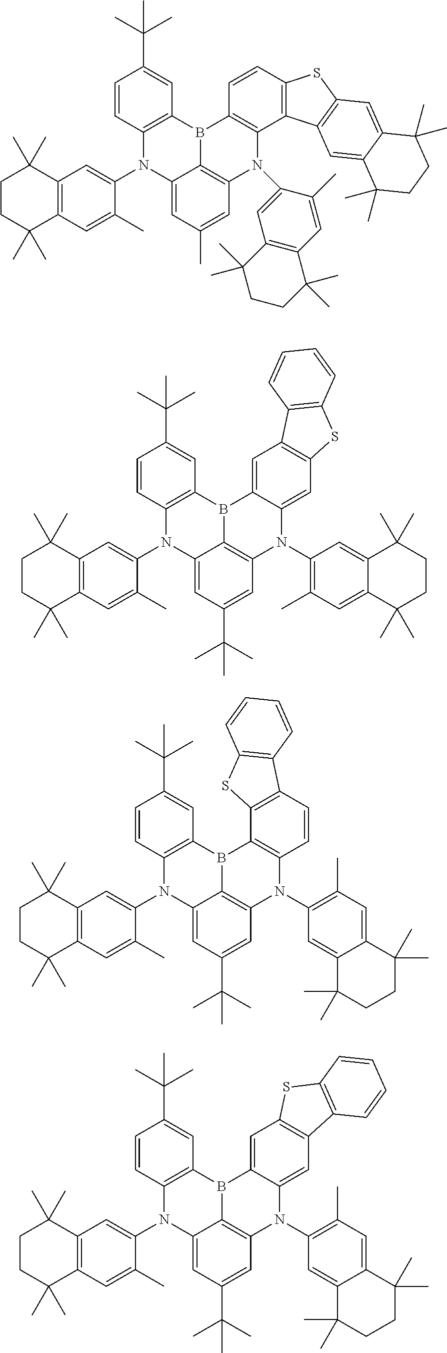

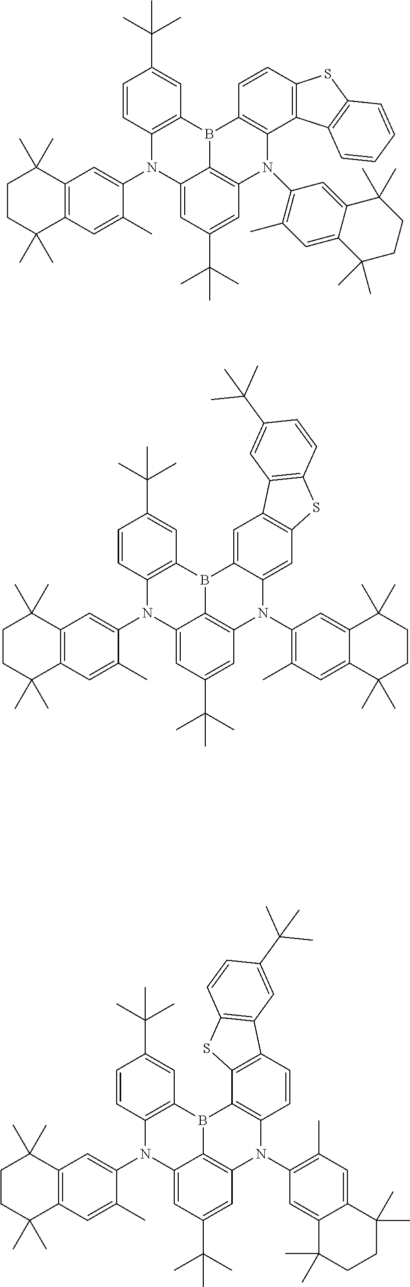 [SMILES: Cc1cc2c(cc1N1c3ccc(C(C)(C)C)cc3B3c4ccc5sc6ccccc6c5c4N(c4cc5c(cc4C)C(C)(C)CCC5(C)C)c4cc(C(C)(C)C)cc1c43)C(C)(C)CCC2(C)C ; Cc1cc2c(cc1N1c3ccc(C(C)(C)C)cc3B3c4cc5c(cc4N(c4cc6c(cc4C)C(C)(C)CCC6(C)C)c4cc(C(C)(C)C)cc1c43)sc1ccc(C(C)(C)C)cc15)C(C)(C)CCC2(C)C ; Cc1cc2c(cc1N1c3ccc(C(C)(C)C)cc3B3c4c1cc(C(C)(C)C)cc4N(c1cc4c(cc1C)C(C)(C)CCC4(C)C)c1ccc4c(sc5ccc(C(C)(C)C)cc54)c13)C(C)(C)CCC2(C)C]

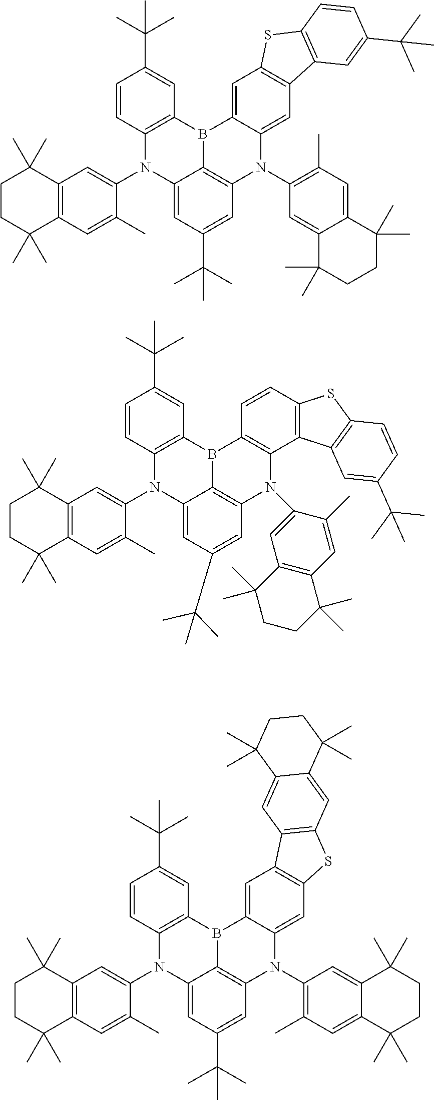

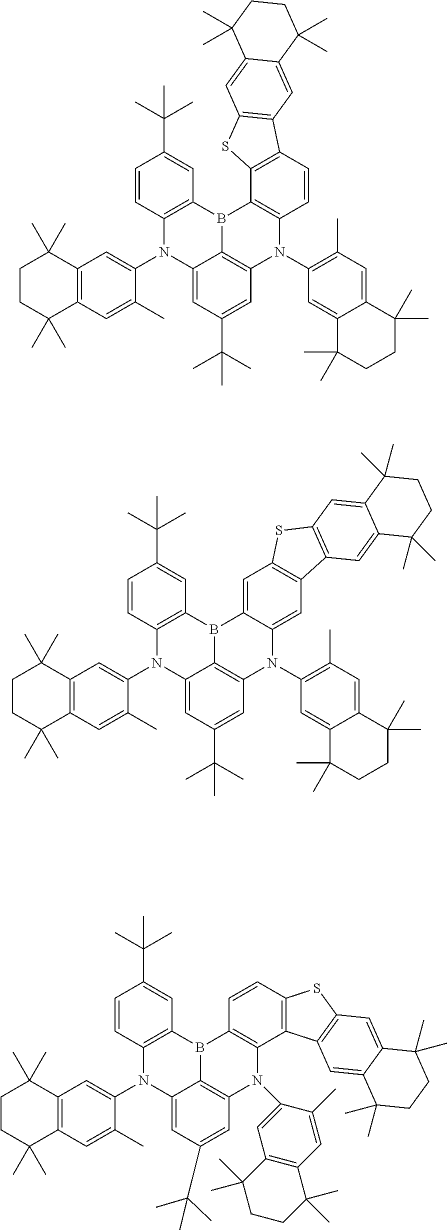 [SMILES: Cc1cc2c(cc1N1c3ccc(C(C)(C)C)cc3B3c4c1cc(C(C)(C)C)cc4N(c1cc4c(cc1C)C(C)(C)CCC4(C)C)c1ccc4c(sc5cc6c(cc54)C(C)(C)CCC6(C)C)c13)C(C)(C)CCC2(C)C ; Cc1cc2c(cc1N1c3ccc(C(C)(C)C)cc3B3c4cc5sc6cc7c(cc6c5cc4N(c4cc5c(cc4C)C(C)(C)CCC5(C)C)c4cc(C(C)(C)C)cc1c43)C(C)(C)CCC7(C)C)C(C)(C)CCC2(C)C ; Cc1cc2c(cc1N1c3ccc(C(C)(C)C)cc3B3c4ccc5sc6cc7c(cc6c5c4N(c4cc5c(cc4C)C(C)(C)CCC5(C)C)c4cc(C(C)(C)C)cc1c43)C(C)(C)CCC7(C)C)C(C)(C)CCC2(C)C]

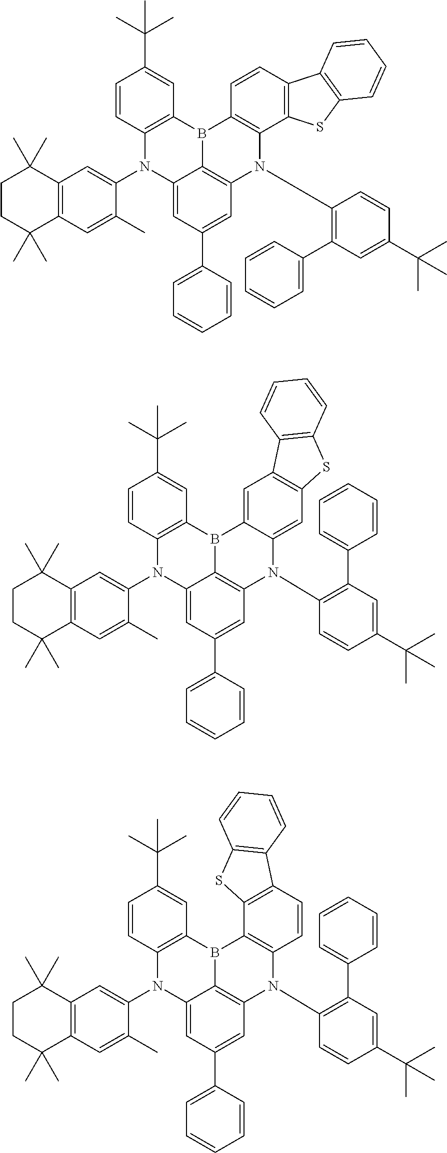 [SMILES: Cc1cc2c(cc1N1c3ccc(C(C)(C)C)cc3B3c4ccc5c(sc6ccccc65)c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6ccccc6)cc1c43)sc1ccccc15)C(C)(C)CCC2(C)C ; Cc1cc2c(cc1N1c3ccc(C(C)(C)C)cc3B3c4c1cc(-c1ccccc1)cc4N(c1ccc(C(C)(C)C)cc1-c1ccccc1)c1ccc4c(sc5ccccc54)c13)C(C)(C)CCC2(C)C]

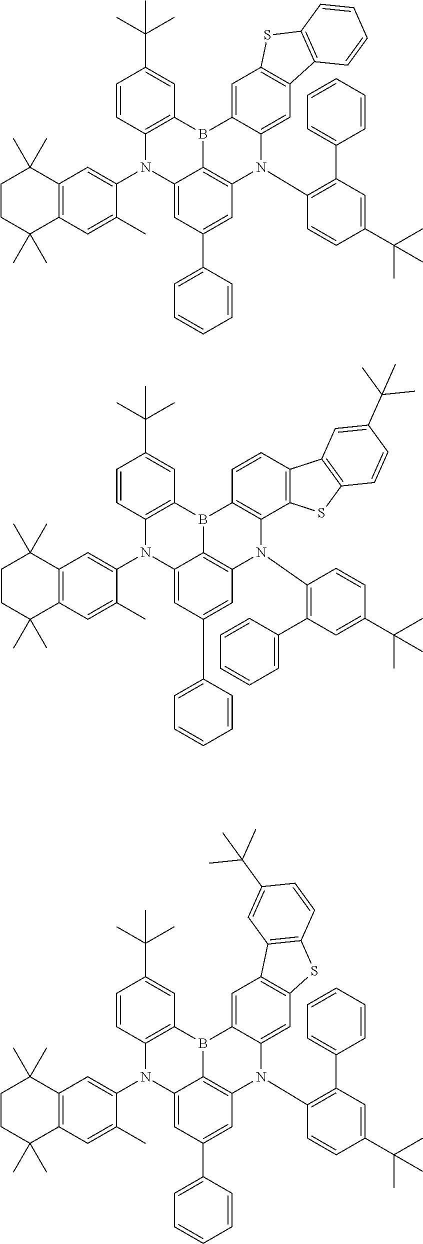 [SMILES: Cc1cc2c(cc1N1c3ccc(C(C)(C)C)cc3B3c4cc5sc6ccccc6c5cc4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6ccccc6)cc1c43)sc1ccc(C(C)(C)C)cc15)C(C)(C)CCC2(C)C]

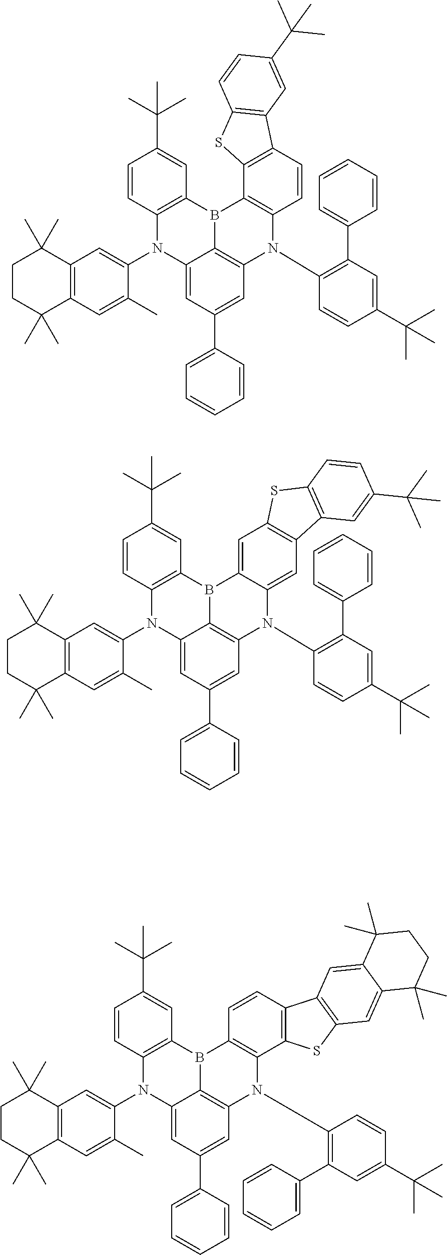 [SMILES: Cc1cc2c(cc1N1c3ccc(C(C)(C)C)cc3B3c4c1cc(-c1ccccc1)cc4N(c1ccc(C(C)(C)C)cc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4cc5sc6ccc(C(C)(C)C)cc6c5cc4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccc(C(C)(C)C)cc4-c4ccccc4)c4cc(-c5ccccc5)cc1c43)C(C)(C)CCC2(C)C]

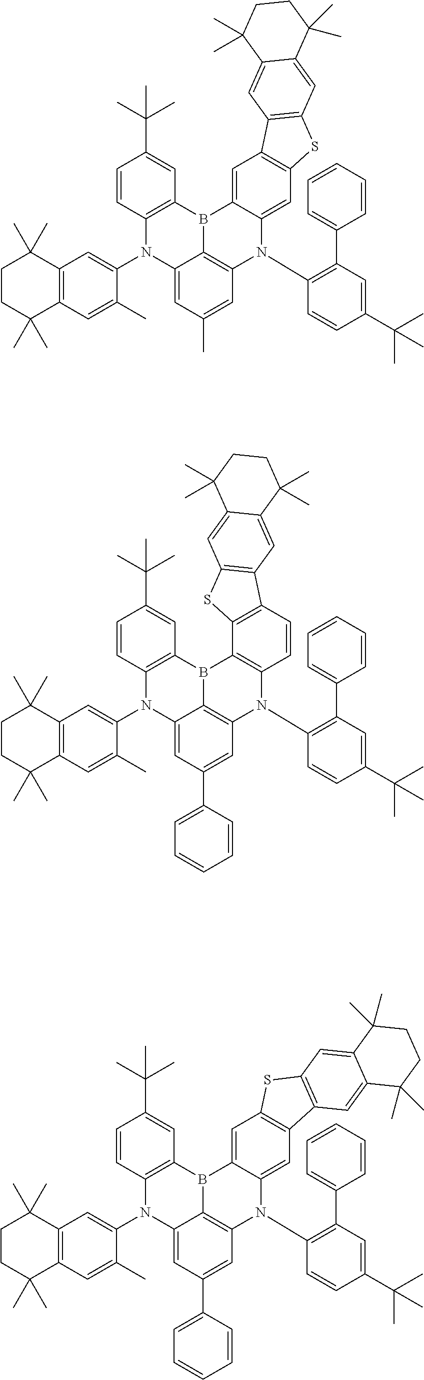 [SMILES: Cc1cc2c3c(c1)N(c1ccc(C(C)(C)C)cc1-c1ccccc1)c1cc4sc5cc6c(cc5c4cc1B3c1cc(C(C)(C)C)ccc1N2c1cc2c(cc1C)C(C)(C)CCC2(C)C)C(C)(C)CCC6(C)C ; Cc1cc2c(cc1N1c3ccc(C(C)(C)C)cc3B3c4c1cc(-c1ccccc1)cc4N(c1ccc(C(C)(C)C)cc1-c1ccccc1)c1ccc4c(sc5cc6c(cc54)C(C)(C)CCC6(C)C)c13)C(C)(C)CCC2(C)C ; Cc1cc2c(cc1N1c3ccc(C(C)(C)C)cc3B3c4cc5sc6cc7c(cc6c5cc4N(c4ccc(C(C)(C)C)cc4-c4ccccc4)c4cc(-c5ccccc5)cc1c43)C(C)(C)CCC7(C)C)C(C)(C)CCC2(C)C]

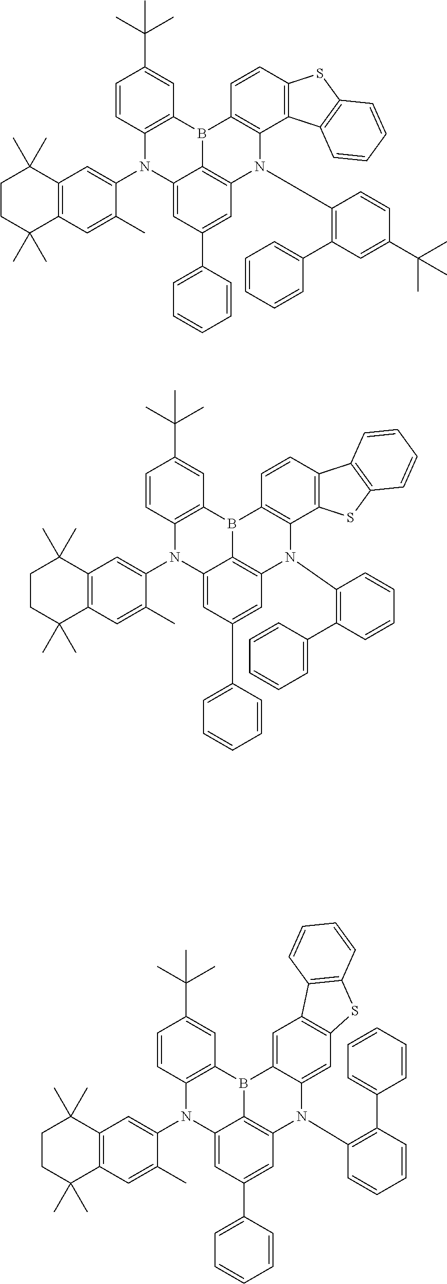 [SMILES: Cc1cc2c(cc1N1c3ccc(C(C)(C)C)cc3B3c4ccc5sc6ccccc6c5c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccccc65)c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(-c6ccccc6)cc1c43)sc1ccccc15)C(C)(C)CCC2(C)C]

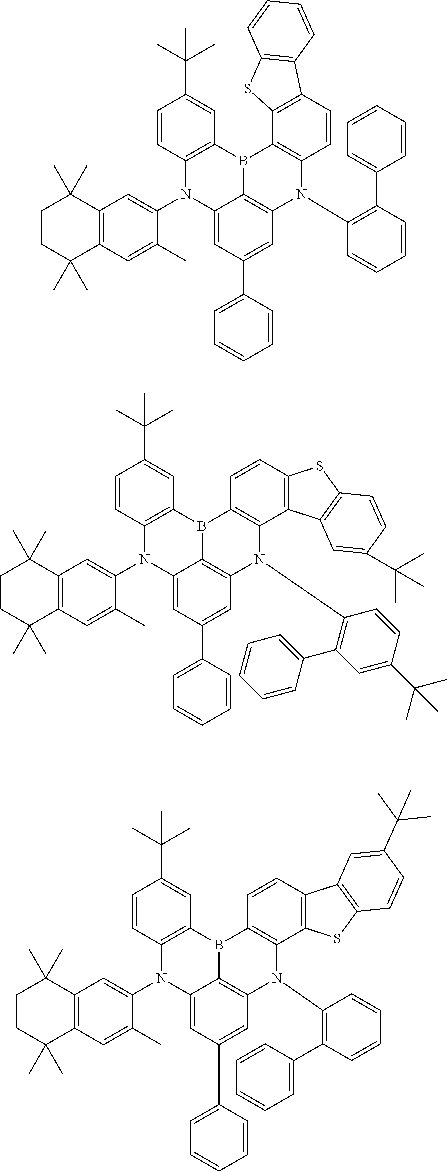 [SMILES: Cc1cc2c(cc1N1c3ccc(C(C)(C)C)cc3B3c4c1cc(-c1ccccc1)cc4N(c1ccccc1-c1ccccc1)c1ccc4c(sc5ccccc54)c13)C(C)(C)CCC2(C)C ; Cc1cc2c(cc1N1c3ccc(C(C)(C)C)cc3B3c4ccc5sc6ccc(C(C)(C)C)cc6c5c4N(c4ccc(C(C)(C)C)cc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4-c4ccccc4)c4cc(-c5ccccc5)cc1c43)C(C)(C)CCC2(C)C]

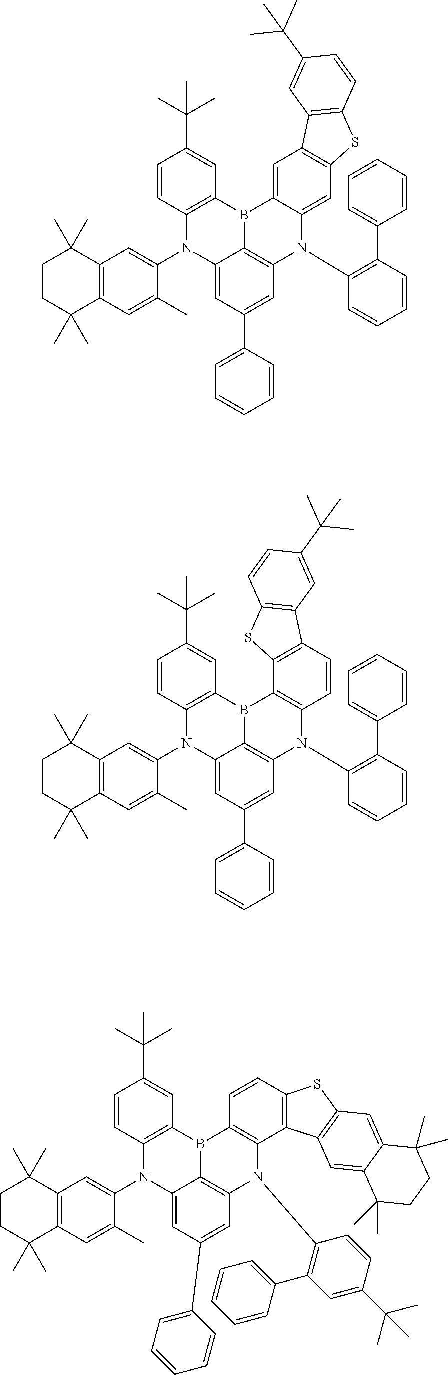 [SMILES: Cc1cc2c(cc1N1c3ccc(C(C)(C)C)cc3B3c4cc5c(cc4N(c4ccccc4-c4ccccc4)c4cc(-c6ccccc6)cc1c43)sc1ccc(C(C)(C)C)cc15)C(C)(C)CCC2(C)C ; Cc1cc2c(cc1N1c3ccc(C(C)(C)C)cc3B3c4c1cc(-c1ccccc1)cc4N(c1ccccc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4ccc5sc6cc7c(cc6c5c4N(c4ccc(C(C)(C)C)cc4-c4ccccc4)c4cc(-c5ccccc5)cc1c43)C(C)(C)CCC7(C)C)C(C)(C)CCC2(C)C]

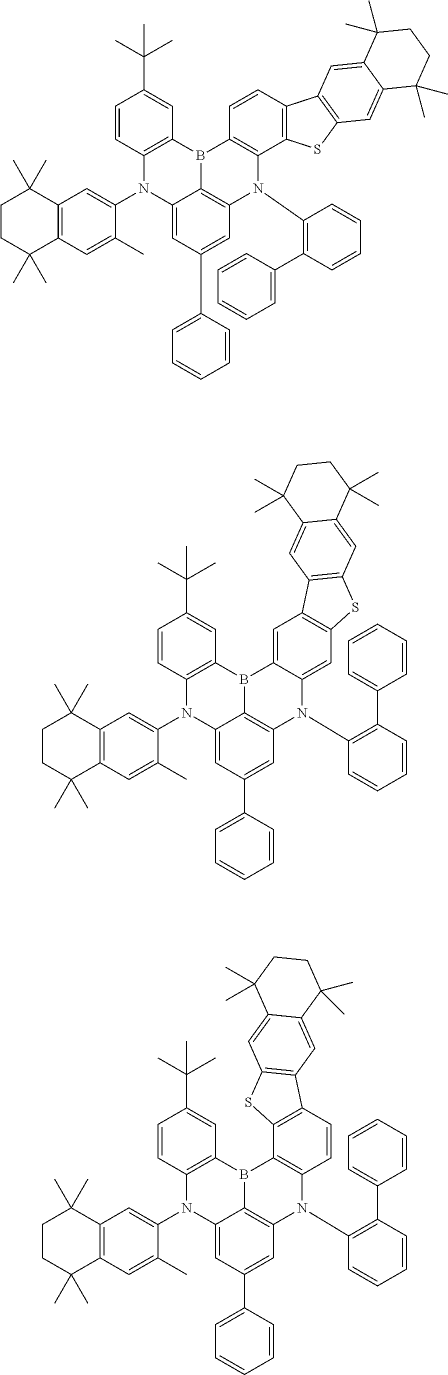 [SMILES: Cc1cc2c(cc1N1c3ccc(C(C)(C)C)cc3B3c4ccc5c(sc6cc7c(cc65)C(C)(C)CCC7(C)C)c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(-c6ccccc6)cc1c43)sc1cc3c(cc15)C(C)(C)CCC3(C)C)C(C)(C)CCC2(C)C ; Cc1cc2c(cc1N1c3ccc(C(C)(C)C)cc3B3c4c1cc(-c1ccccc1)cc4N(c1ccccc1-c1ccccc1)c1ccc4c(sc5cc6c(cc54)C(C)(C)CCC6(C)C)c13)C(C)(C)CCC2(C)C]

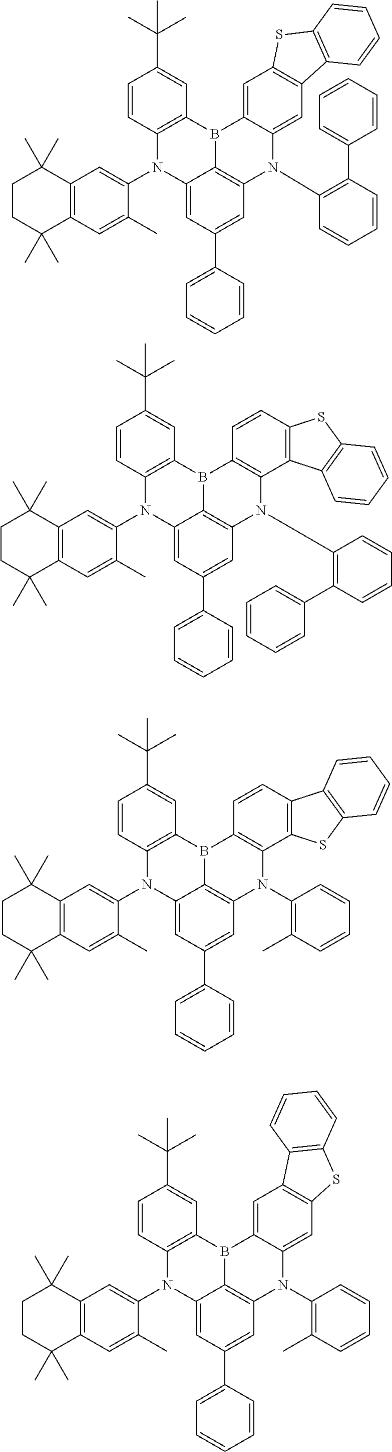

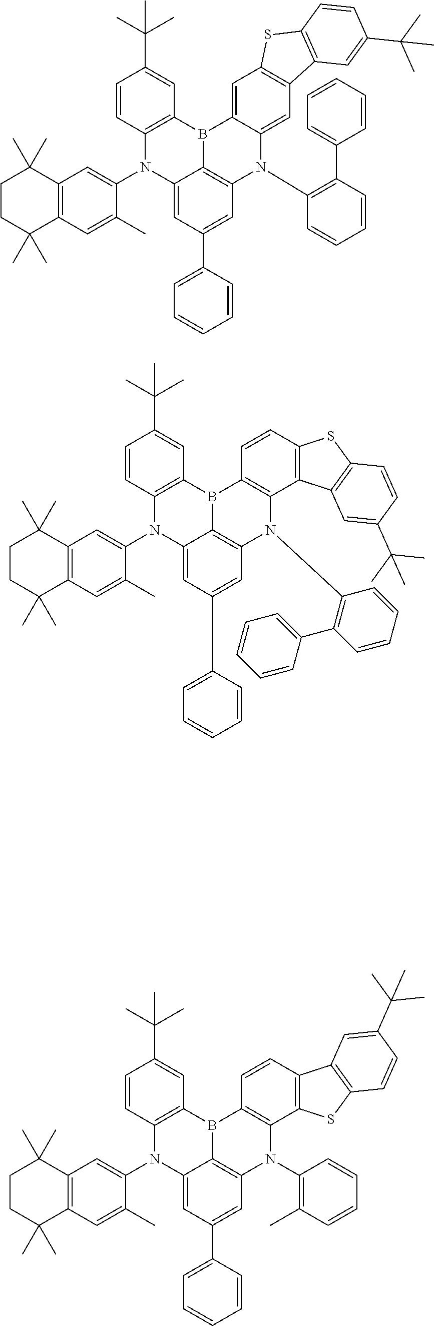 [SMILES: Cc1cc2c(cc1N1c3ccc(C(C)(C)C)cc3B3c4cc5sc6ccc(C(C)(C)C)cc6c5cc4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4ccc5sc6ccc(C(C)(C)C)cc6c5c4N(c4ccccc4-c4ccccc4)c4cc(-c5ccccc5)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccccc4C)c4cc(-c5ccccc5)cc1c43)C(C)(C)CCC2(C)C]

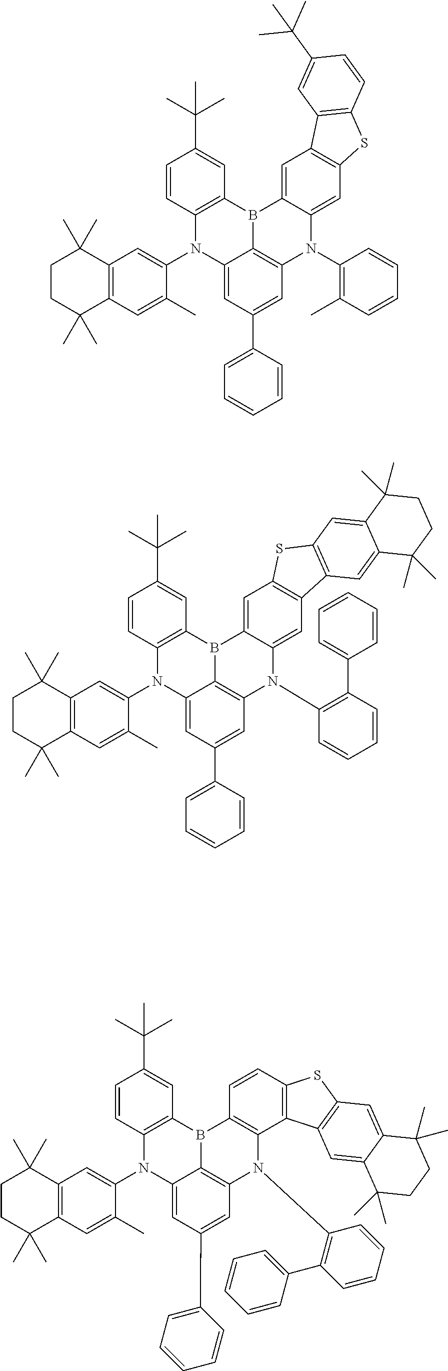 [SMILES: Cc1ccccc1N1c2cc3sc4ccc(C(C)(C)C)cc4c3cc2B2c3cc(C(C)(C)C)ccc3N(c3cc4c(cc3C)C(C)(C)CCC4(C)C)c3cc(-c4ccccc4)cc1c32 ; Cc1cc2c(cc1N1c3ccc(C(C)(C)C)cc3B3c4cc5sc6cc7c(cc6c5cc4N(c4ccccc4-c4ccccc4)c4cc(-c5ccccc5)cc1c43)C(C)(C)CCC7(C)C)C(C)(C)CCC2(C)C ; Cc1cc2c(cc1N1c3ccc(C(C)(C)C)cc3B3c4ccc5sc6cc7c(cc6c5c4N(c4ccccc4-c4ccccc4)c4cc(-c5ccccc5)cc1c43)C(C)(C)CCC7(C)C)C(C)(C)CCC2(C)C]

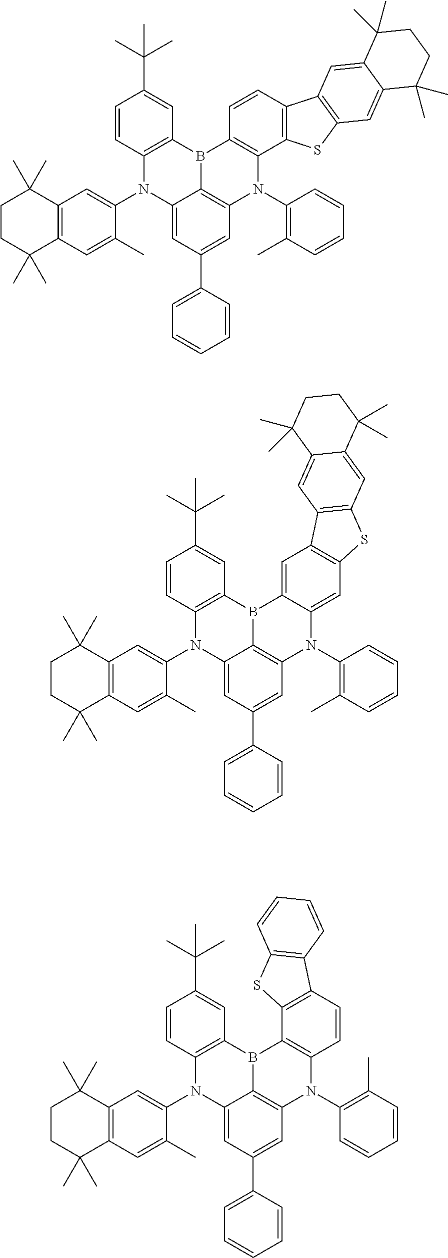 [SMILES: Cc1cc2c(cc1N1c3ccc(C(C)(C)C)cc3B3c4ccc5c(sc6cc7c(cc65)C(C)(C)CCC7(C)C)c4N(c4ccccc4C)c4cc(-c5ccccc5)cc1c43)C(C)(C)CCC2(C)C ; Cc1ccccc1N1c2cc3sc4cc5c(cc4c3cc2B2c3cc(C(C)(C)C)ccc3N(c3cc4c(cc3C)C(C)(C)CCC4(C)C)c3cc(-c4ccccc4)cc1c32)C(C)(C)CCC5(C)C ; Cc1cc2c(cc1N1c3ccc(C(C)(C)C)cc3B3c4c1cc(-c1ccccc1)cc4N(c1ccccc1C)c1ccc4c(sc5ccccc54)c13)C(C)(C)CCC2(C)C]

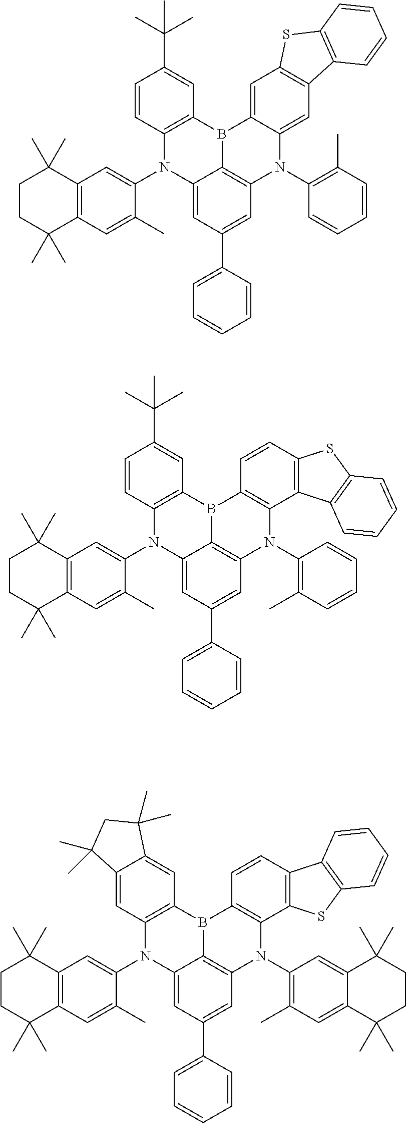 [SMILES: Cc1ccccc1N1c2cc3c(cc2B2c4cc(C(C)(C)C)ccc4N(c4cc5c(cc4C)C(C)(C)CCC5(C)C)c4cc(-c5ccccc5)cc1c42)sc1ccccc13 ; Cc1cc2c(cc1N1c3ccc(C(C)(C)C)cc3B3c4ccc5sc6ccccc6c5c4N(c4ccccc4C)c4cc(-c5ccccc5)cc1c43)C(C)(C)CCC2(C)C ; Cc1cc2c(cc1N1c3cc4c(cc3B3c5ccc6c(sc7ccccc76)c5N(c5cc6c(cc5C)C(C)(C)CCC6(C)C)c5cc(-c6ccccc6)cc1c53)C(C)(C)CC4(C)C)C(C)(C)CCC2(C)C]

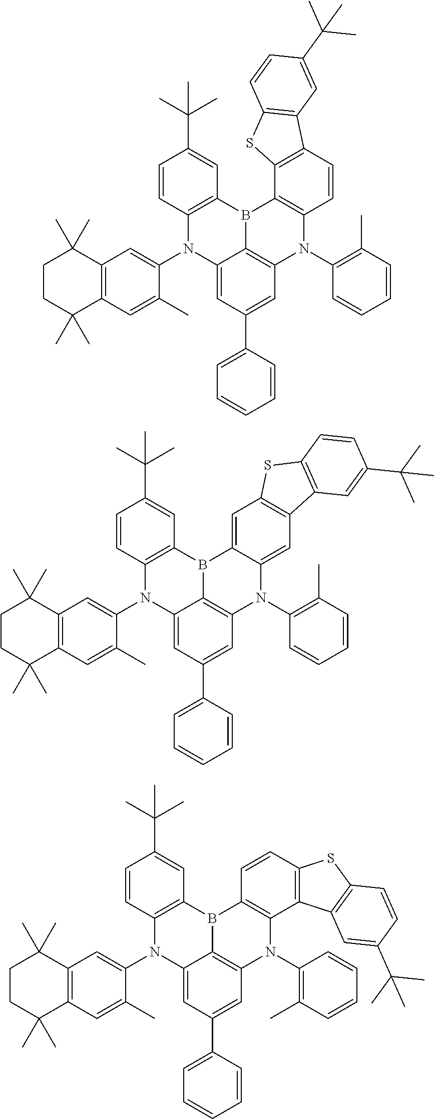

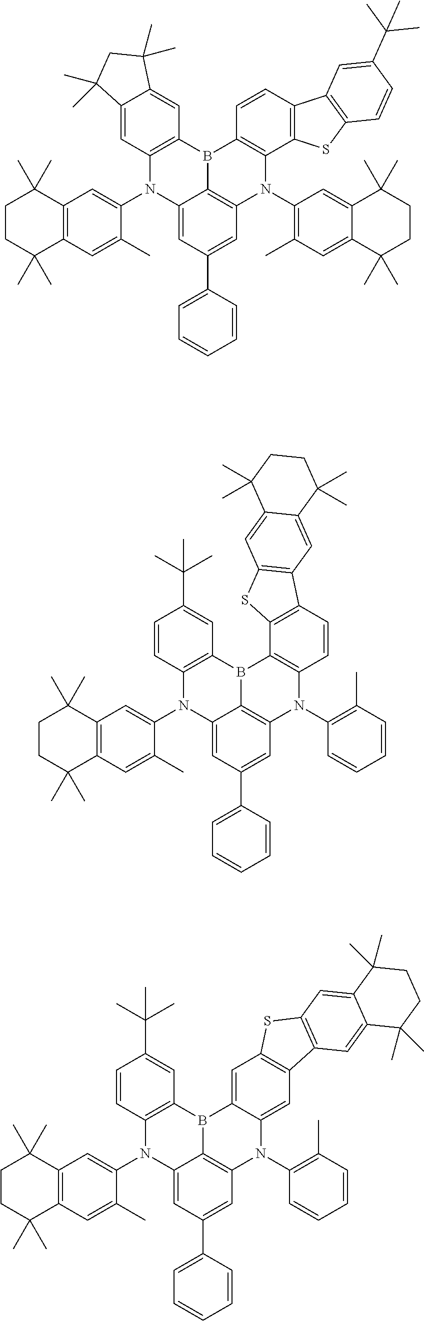 [SMILES: Cc1cc2c(cc1N1c3cc4c(cc3B3c5ccc6c(sc7ccc(C(C)(C)C)cc76)c5N(c5cc6c(cc5C)C(C)(C)CCC6(C)C)c5cc(-c6ccccc6)cc1c53)C(C)(C)CC4(C)C)C(C)(C)CCC2(C)C ; Cc1cc2c(cc1N1c3ccc(C(C)(C)C)cc3B3c4c1cc(-c1ccccc1)cc4N(c1ccccc1C)c1ccc4c(sc5cc6c(cc54)C(C)(C)CCC6(C)C)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5ccccc5)cc1c42)sc1cc2c(cc13)C(C)(C)CCC2(C)C]

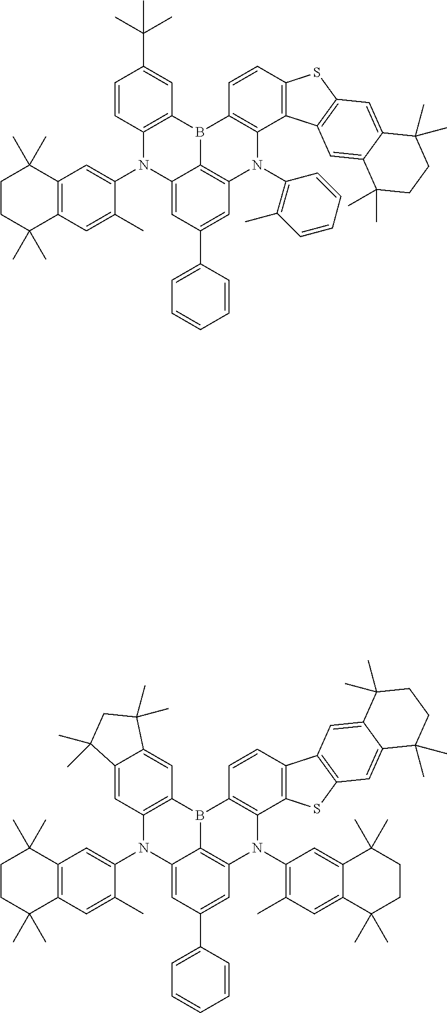 [SMILES: Cc1cc2c(cc1N1c3ccc(C(C)(C)C)cc3B3c4ccc5sc6cc7c(cc6c5c4N(c4ccccc4C)c4cc(-c5ccccc5)cc1c43)C(C)(C)CCC7(C)C)C(C)(C)CCC2(C)C ; Cc1cc2c(cc1N1c3cc4c(cc3B3c5ccc6c(sc7cc8c(cc76)C(C)(C)CCC8(C)C)c5N(c5cc6c(cc5C)C(C)(C)CCC6(C)C)c5cc(-c6ccccc6)cc1c53)C(C)(C)CC4(C)C)C(C)(C)CCC2(C)C]

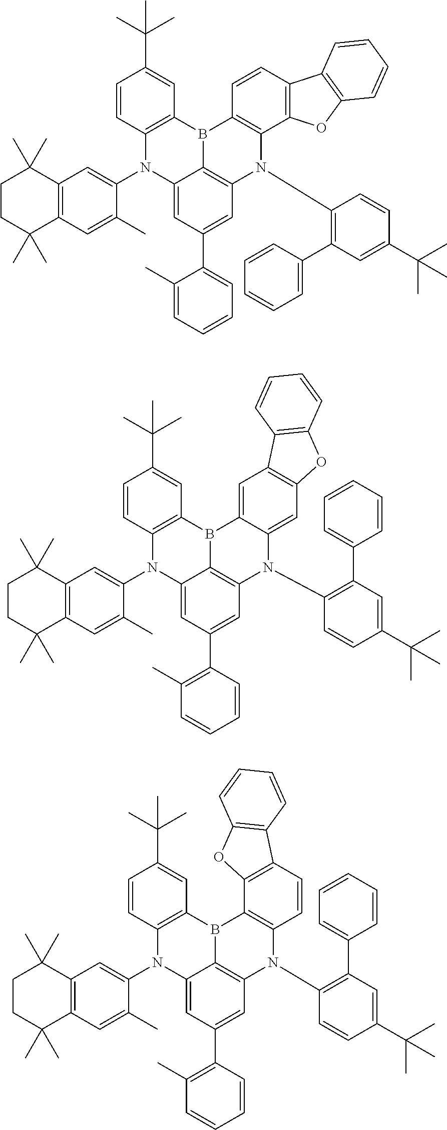

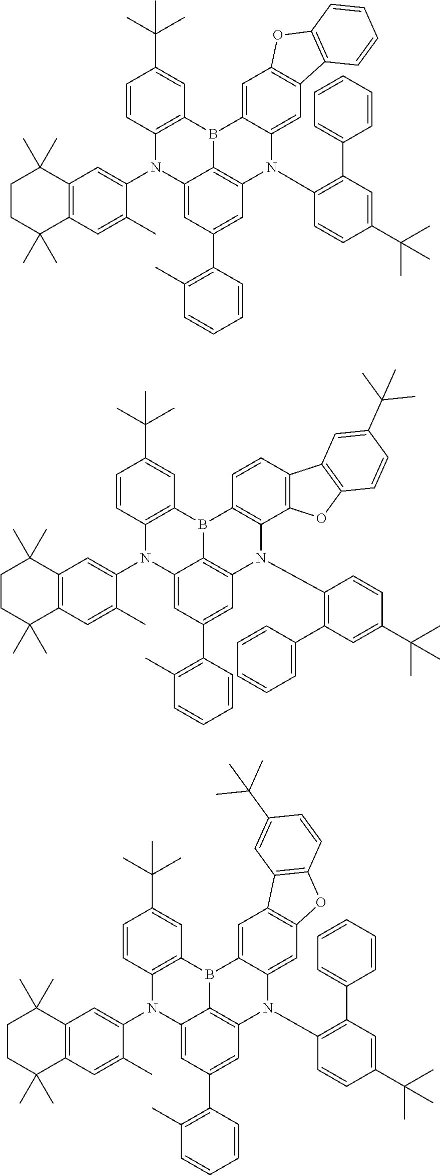 [SMILES: Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)oc1ccccc14 ; Cc1ccccc1-c1cc2c3c(c1)N(c1ccc(C(C)(C)C)cc1-c1ccccc1)c1c(ccc4c1oc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4oc5ccc(C(C)(C)C)cc5c4cc1B3c1cc(C(C)(C)C)ccc1N2c1cc2c(cc1C)C(C)(C)CCC2(C)C]

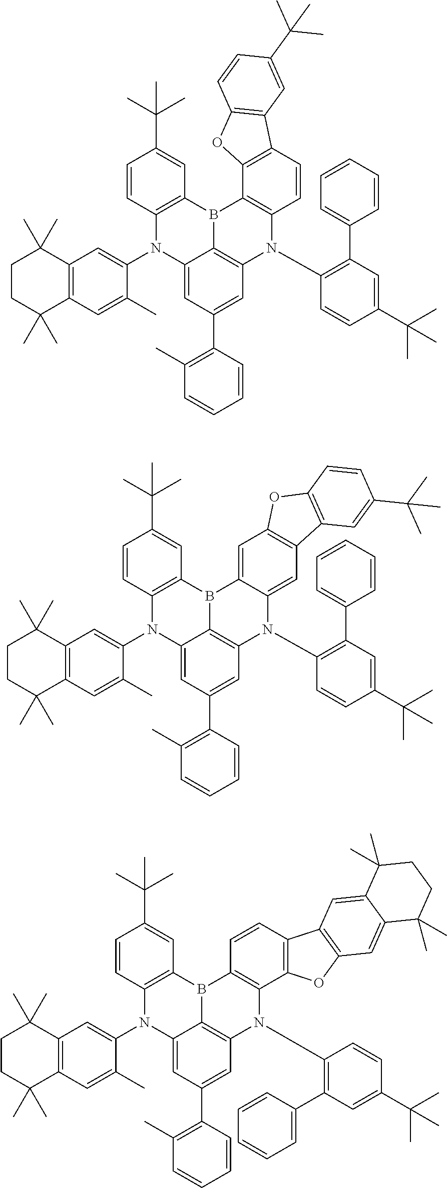 [SMILES: Cc1ccccc1-c1cc2c3c(c1)N(c1ccc(C(C)(C)C)cc1-c1ccccc1)c1ccc4c(oc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)oc1ccc(C(C)(C)C)cc14 ; Cc1ccccc1-c1cc2c3c(c1)N(c1ccc(C(C)(C)C)cc1-c1ccccc1)c1c(ccc4c1oc1cc5c(cc14)C(C)(C)CCC5(C)C)B3c1cc(C(C)(C)C)ccc1N2c1cc2c(cc1C)C(C)(C)CCC2(C)C]

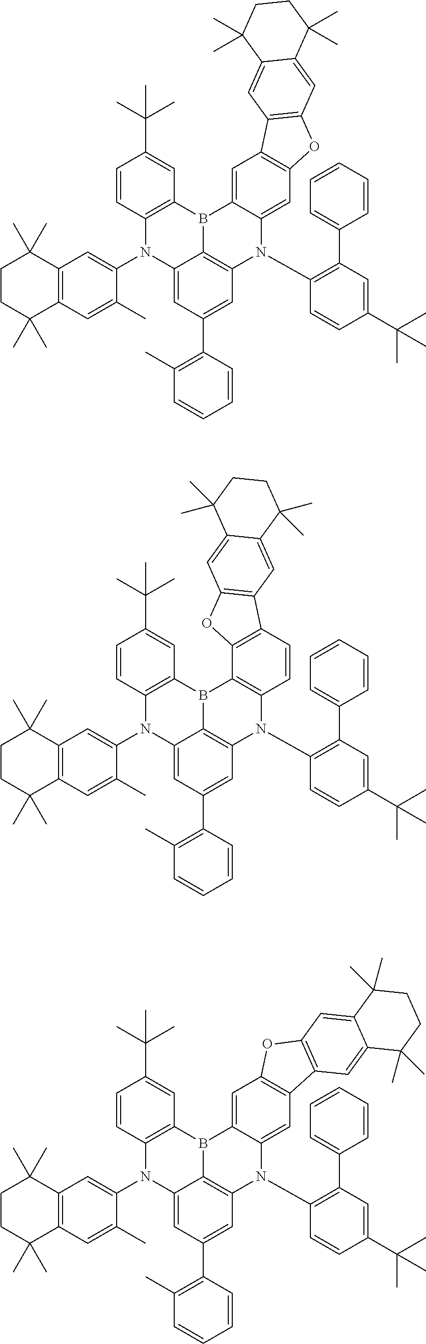 [SMILES: Cc1ccccc1-c1cc2c3c(c1)N(c1ccc(C(C)(C)C)cc1-c1ccccc1)c1cc4oc5cc6c(cc5c4cc1B3c1cc(C(C)(C)C)ccc1N2c1cc2c(cc1C)C(C)(C)CCC2(C)C)C(C)(C)CCC6(C)C ; Cc1ccccc1-c1cc2c3c(c1)N(c1ccc(C(C)(C)C)cc1-c1ccccc1)c1ccc4c(oc5cc6c(cc54)C(C)(C)CCC6(C)C)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)oc1cc2c(cc14)C(C)(C)CCC2(C)C]

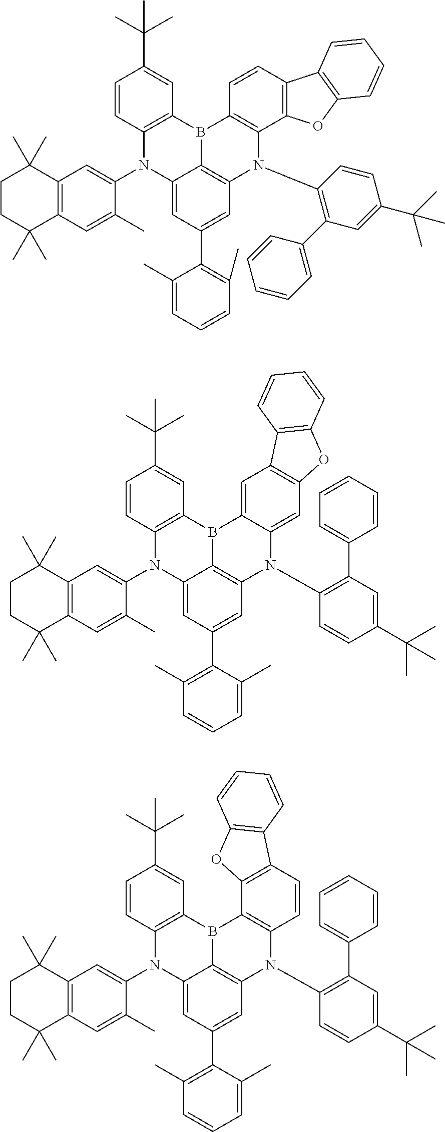

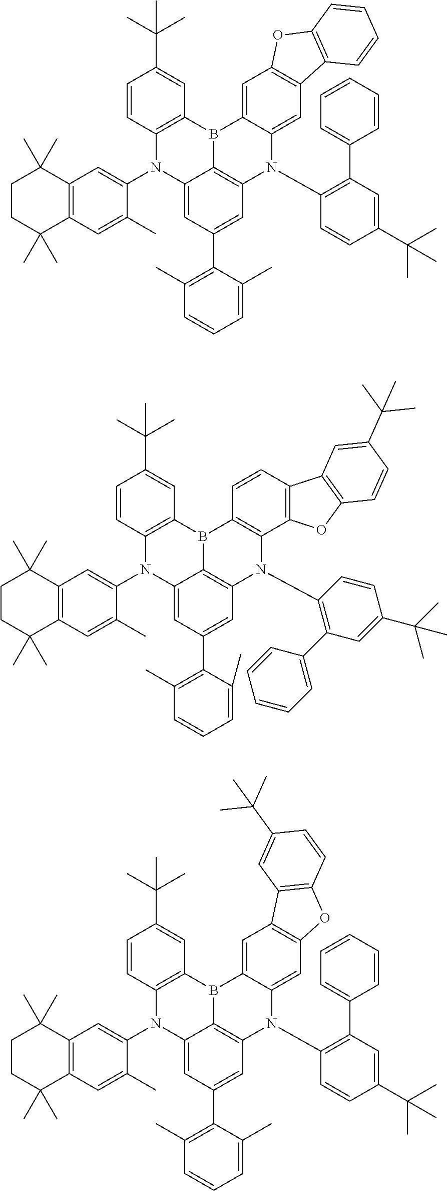 [SMILES: Cc1cc2c(cc1N1c3ccc(C(C)(C)C)cc3B3c4cc5oc6ccccc6c5cc4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4cc5c(cc4N(c4ccc(C(C)(C)C)cc4-c4ccccc4)c4cc(-c6c(C)cccc6C)cc1c43)oc1ccc(C(C)(C)C)cc15)C(C)(C)CCC2(C)C]

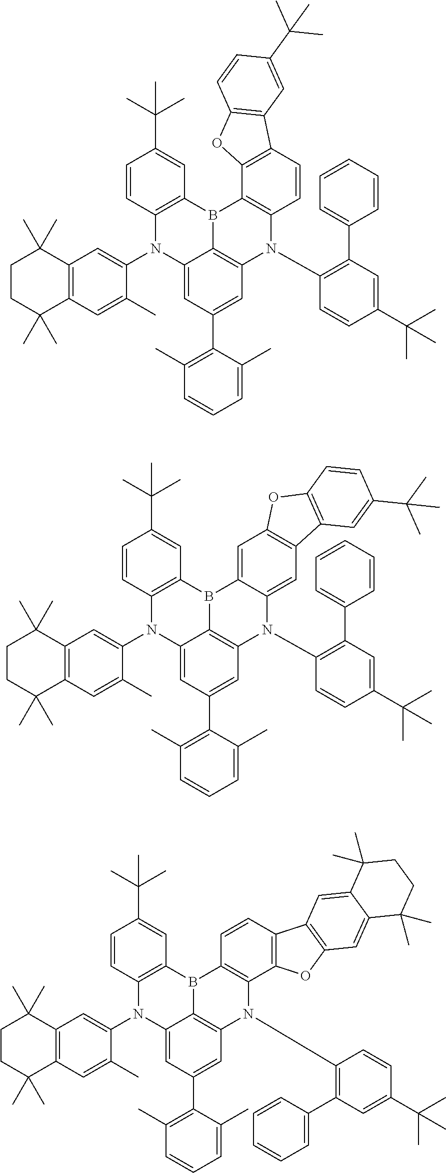 [SMILES: Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(oc5ccc(C(C)(C)C)cc54)c13)C(C)(C)CCC2(C)C ; Cc1cc2c(cc1N1c3ccc(C(C)(C)C)cc3B3c4cc5oc6ccc(C(C)(C)C)cc6c5cc4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6cc7c(cc65)C(C)(C)CCC7(C)C)c4N(c4ccc(C(C)(C)C)cc4-c4ccccc4)c4cc(-c5c(C)cccc5C)cc1c43)C(C)(C)CCC2(C)C]

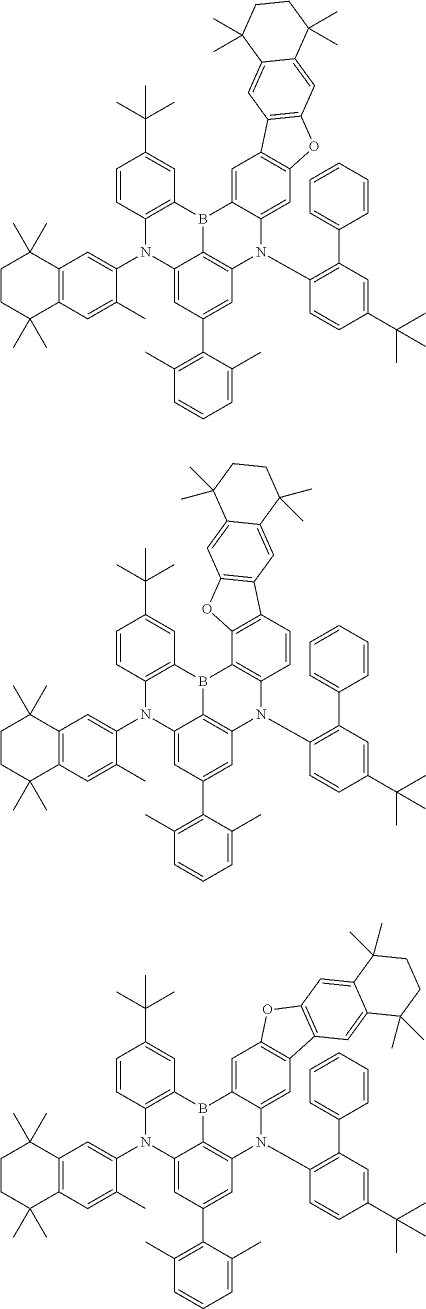 [SMILES: Cc1cc2c(cc1N1c3ccc(C(C)(C)C)cc3B3c4cc5c(cc4N(c4ccc(C(C)(C)C)cc4-c4ccccc4)c4cc(-c6c(C)cccc6C)cc1c43)oc1cc3c(cc15)C(C)(C)CCC3(C)C)C(C)(C)CCC2(C)C ; Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(oc5cc6c(cc54)C(C)(C)CCC6(C)C)c13)C(C)(C)CCC2(C)C ; Cc1cc2c(cc1N1c3ccc(C(C)(C)C)cc3B3c4cc5oc6cc7c(cc6c5cc4N(c4ccc(C(C)(C)C)cc4-c4ccccc4)c4cc(-c5c(C)cccc5C)cc1c43)C(C)(C)CCC7(C)C)C(C)(C)CCC2(C)C]

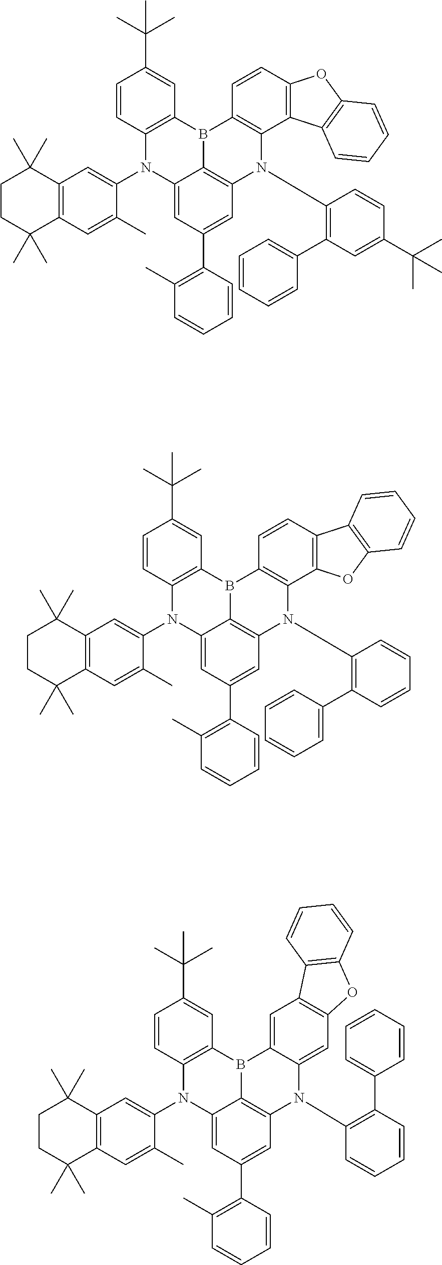 [SMILES: Cc1ccccc1-c1cc2c3c(c1)N(c1ccc(C(C)(C)C)cc1-c1ccccc1)c1c(ccc4oc5ccccc5c14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1oc1ccccc14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4oc5ccccc5c4cc1B3c1cc(C(C)(C)C)ccc1N2c1cc2c(cc1C)C(C)(C)CCC2(C)C]

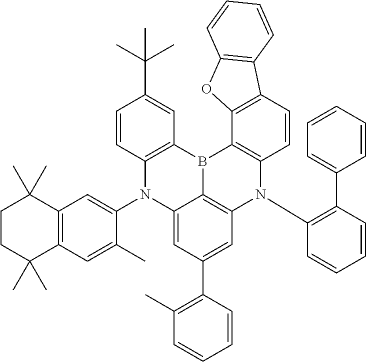 [SMILES: Cc1ccccc1-c1cc2c3c(c1)N(c1ccccc1-c1ccccc1)c1ccc4c(oc5ccccc54)c1B3c1cc(C(C)(C)C)ccc1N2c1cc2c(cc1C)C(C)(C)CCC2(C)C]

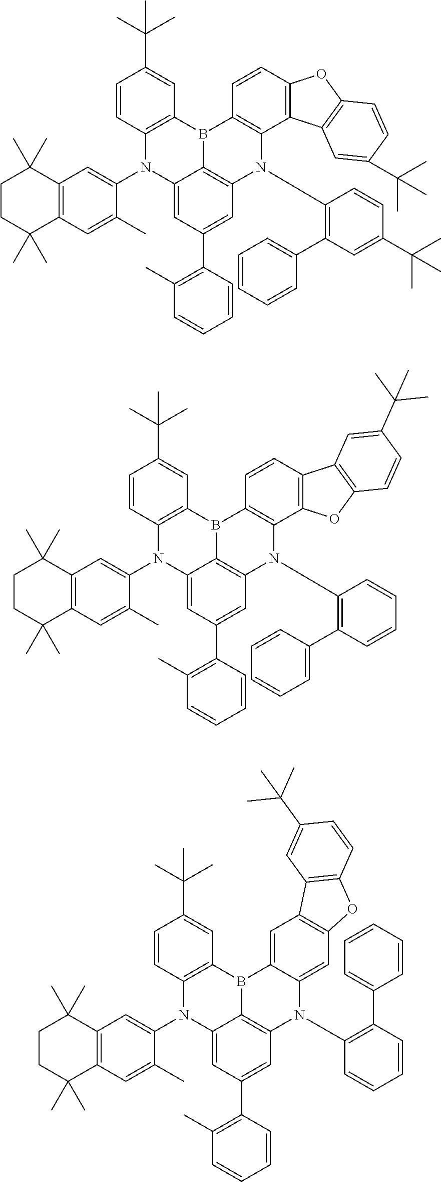 [SMILES: Cc1ccccc1-c1cc2c3c(c1)N(c1ccc(C(C)(C)C)cc1-c1ccccc1)c1c(ccc4oc5ccc(C(C)(C)C)cc5c14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1oc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4oc5ccc(C(C)(C)C)cc5c4cc1B3c1cc(C(C)(C)C)ccc1N2c1cc2c(cc1C)C(C)(C)CCC2(C)C]

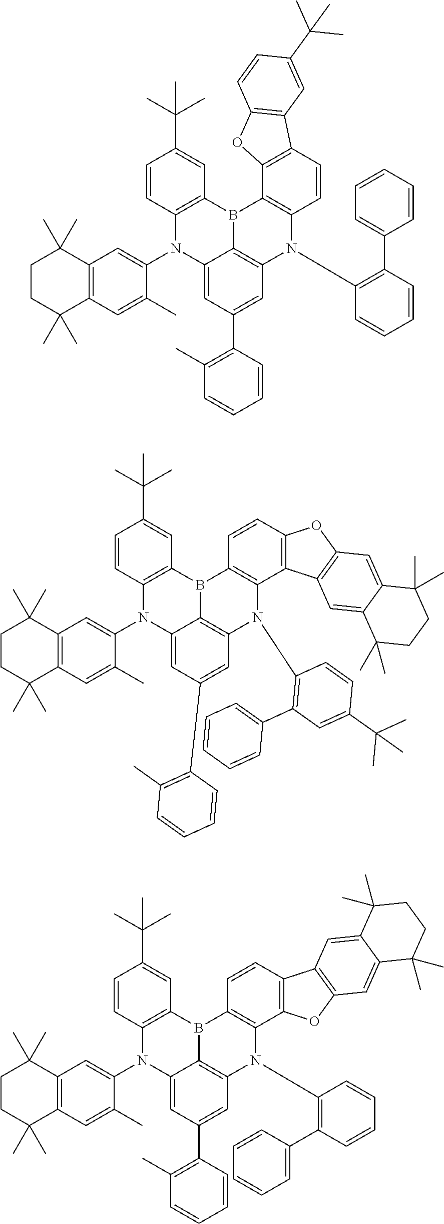 [SMILES: Cc1ccccc1-c1cc2c3c(c1)N(c1ccccc1-c1ccccc1)c1ccc4c(oc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1oc1cc5c(cc14)C(C)(C)CCC5(C)C)B3c1cc(C(C)(C)C)ccc1N2c1cc2c(cc1C)C(C)(C)CCC2(C)C]

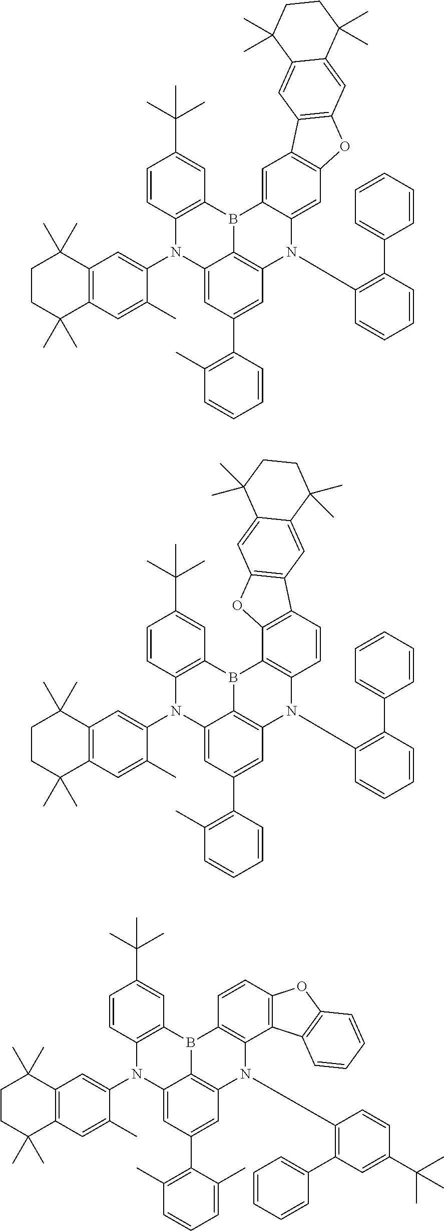

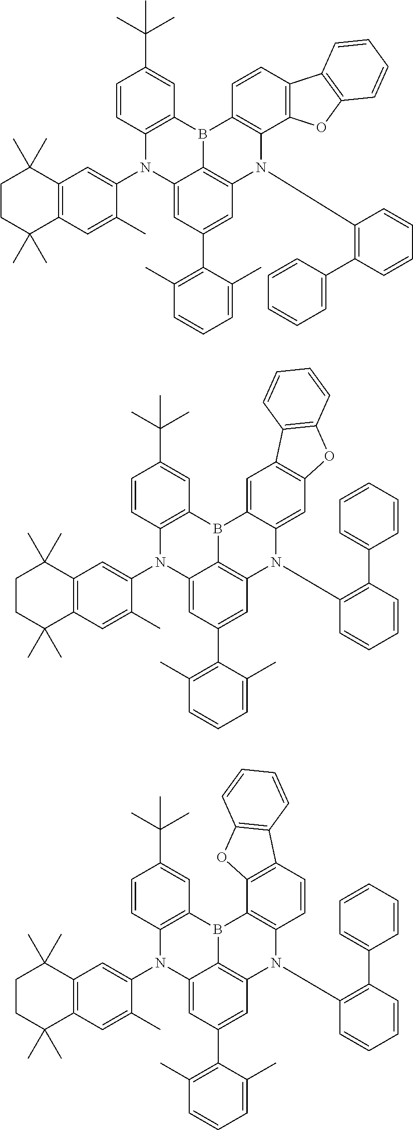

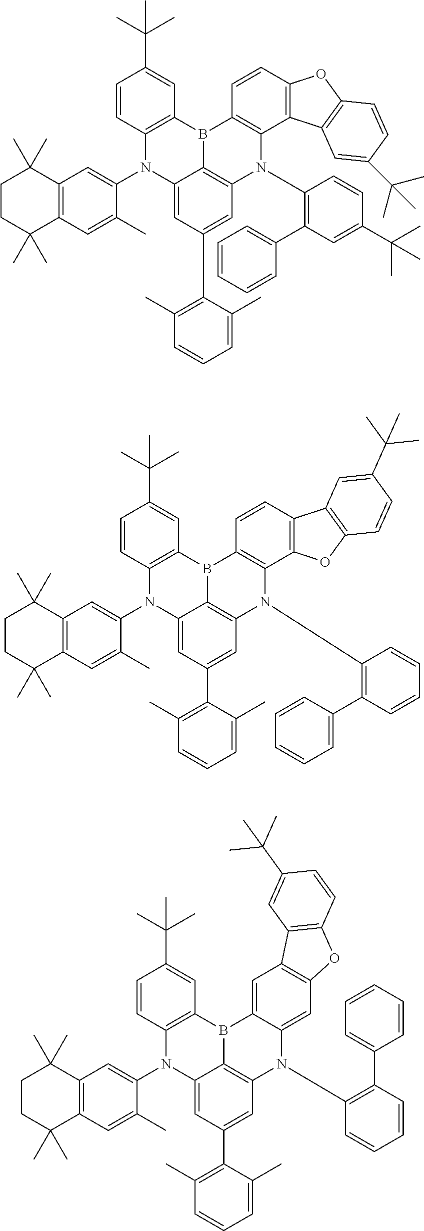 [SMILES: Cc1cc2c(cc1N1c3ccc(C(C)(C)C)cc3B3c4ccc5oc6ccc(C(C)(C)C)cc6c5c4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4cc5c(cc4N(c4ccccc4-c4ccccc4)c4cc(-c6c(C)cccc6C)cc1c43)oc1ccc(C(C)(C)C)cc15)C(C)(C)CCC2(C)C]

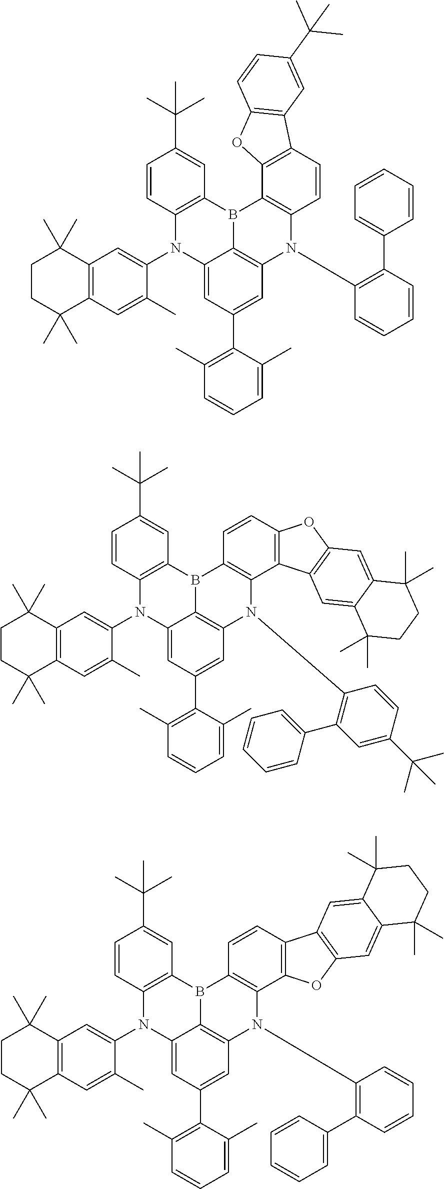 [SMILES: Cc1cc2c(cc1N1c3ccc(C(C)(C)C)cc3B3c4c1cc(-c1c(C)cccc1C)cc4N(c1ccccc1-c1ccccc1)c1ccc4c(oc5ccc(C(C)(C)C)cc54)c13)C(C)(C)CCC2(C)C ; Cc1cc2c(cc1N1c3ccc(C(C)(C)C)cc3B3c4ccc5oc6cc7c(cc6c5c4N(c4ccc(C(C)(C)C)cc4-c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5c(oc6cc7c(cc65)C(C)(C)CCC7(C)C)c4N(c4ccccc4-c4ccccc4)c4cc(-c5c(C)cccc5C)cc1c43)C(C)(C)CCC2(C)C]

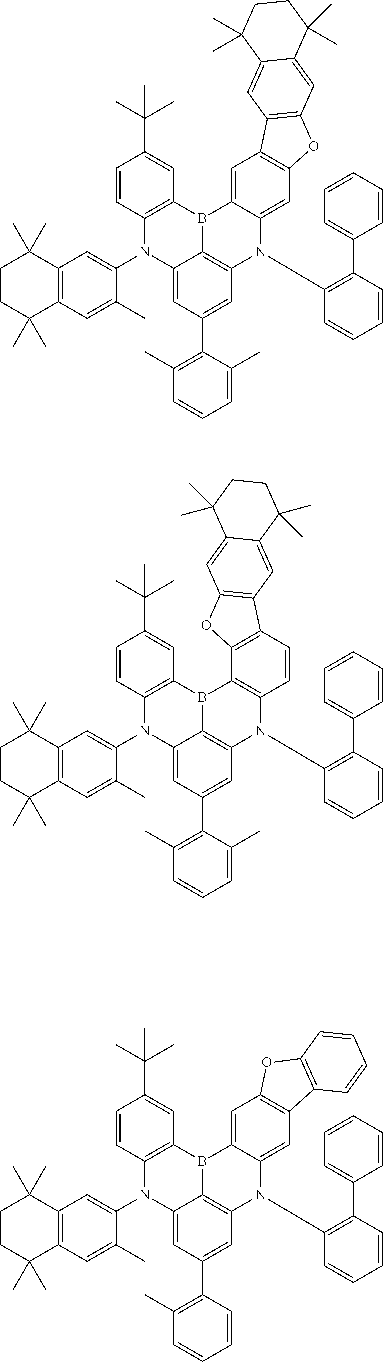 [SMILES: Cc1cc2c(cc1N1c3ccc(C(C)(C)C)cc3B3c4cc5c(cc4N(c4ccccc4-c4ccccc4)c4cc(-c6c(C)cccc6C)cc1c43)oc1cc3c(cc15)C(C)(C)CCC3(C)C)C(C)(C)CCC2(C)C ; Cc1cc2c(cc1N1c3ccc(C(C)(C)C)cc3B3c4c1cc(-c1c(C)cccc1C)cc4N(c1ccccc1-c1ccccc1)c1ccc4c(oc5cc6c(cc54)C(C)(C)CCC6(C)C)c13)C(C)(C)CCC2(C)C ; Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1ccccc14]

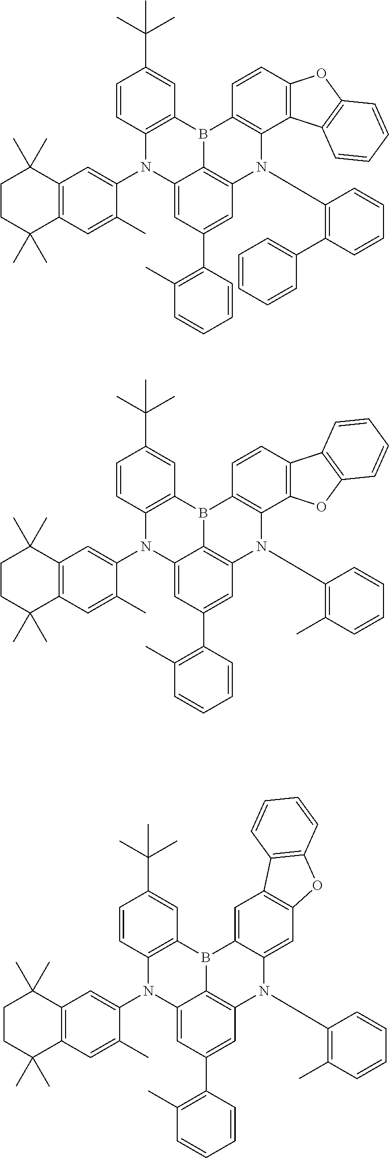 [SMILES: Cc1ccccc1-c1cc2c3c(c1)N(c1ccccc1-c1ccccc1)c1c(ccc4oc5ccccc5c14)B3c1cc(C(C)(C)C)ccc1N2c1cc2c(cc1C)C(C)(C)CCC2(C)C ; Cc1ccccc1-c1cc2c3c(c1)N(c1ccccc1C)c1c(ccc4c1oc1ccccc14)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4oc5ccccc5c4cc1B3c1cc(C(C)(C)C)ccc1N2c1cc2c(cc1C)C(C)(C)CCC2(C)C]

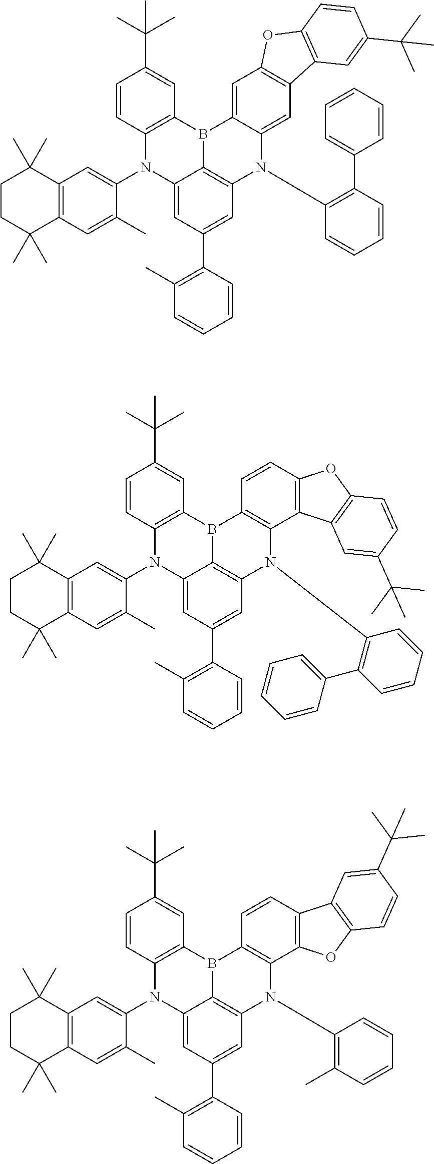 [SMILES: Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1ccc(C(C)(C)C)cc14 ; Cc1ccccc1-c1cc2c3c(c1)N(c1ccccc1-c1ccccc1)c1c(ccc4oc5ccc(C(C)(C)C)cc5c14)B3c1cc(C(C)(C)C)ccc1N2c1cc2c(cc1C)C(C)(C)CCC2(C)C ; Cc1ccccc1-c1cc2c3c(c1)N(c1ccccc1C)c1c(ccc4c1oc1ccc(C(C)(C)C)cc14)B3c1cc(C(C)(C)C)ccc1N2c1cc2c(cc1C)C(C)(C)CCC2(C)C]

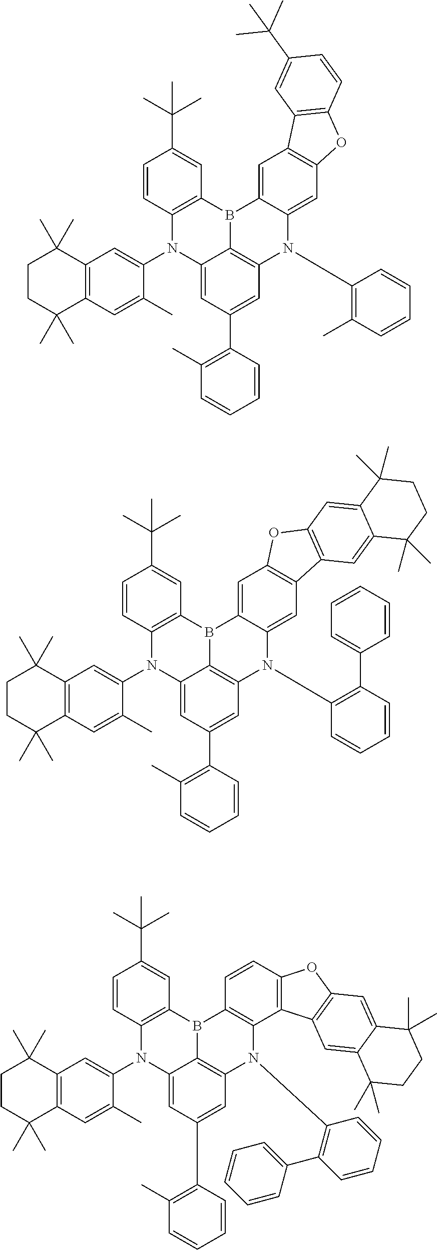 [SMILES: Cc1ccccc1-c1cc2c3c(c1)N(c1ccccc1C)c1cc4oc5ccc(C(C)(C)C)cc5c4cc1B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1ccccc1-c1cc2c3c(c1)N(c1ccccc1-c1ccccc1)c1c(ccc4oc5cc6c(cc5c14)C(C)(C)CCC6(C)C)B3c1cc(C(C)(C)C)ccc1N2c1cc2c(cc1C)C(C)(C)CCC2(C)C]

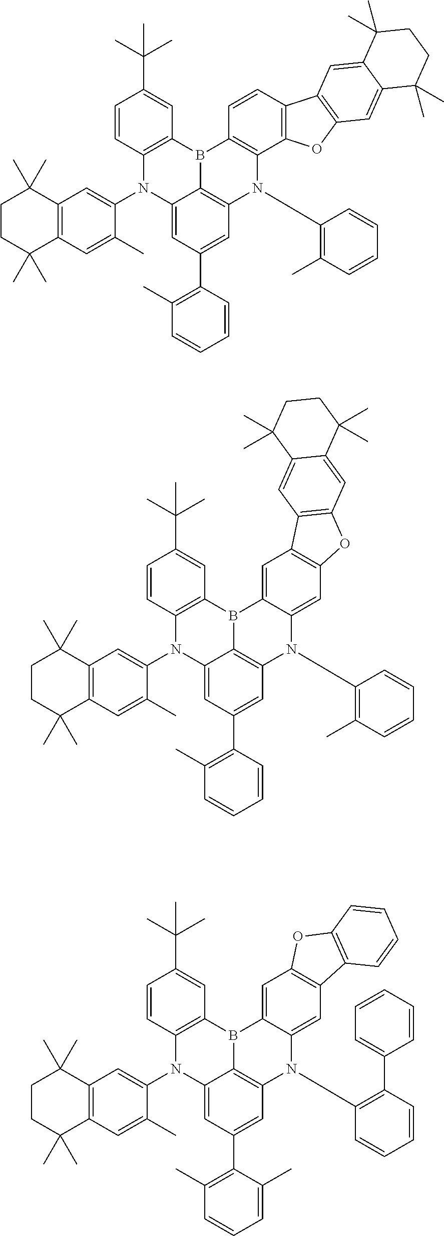 [SMILES: Cc1ccccc1-c1cc2c3c(c1)N(c1ccccc1C)c1c(ccc4c1oc1cc5c(cc14)C(C)(C)CCC5(C)C)B3c1cc(C(C)(C)C)ccc1N2c1cc2c(cc1C)C(C)(C)CCC2(C)C ; Cc1ccccc1-c1cc2c3c(c1)N(c1ccccc1C)c1cc4oc5cc6c(cc5c4cc1B3c1cc(C(C)(C)C)ccc1N2c1cc2c(cc1C)C(C)(C)CCC2(C)C)C(C)(C)CCC6(C)C ; Cc1cc2c(cc1N1c3ccc(C(C)(C)C)cc3B3c4cc5oc6ccccc6c5cc4N(c4ccccc4-c4ccccc4)c4cc(-c5c(C)cccc5C)cc1c43)C(C)(C)CCC2(C)C]

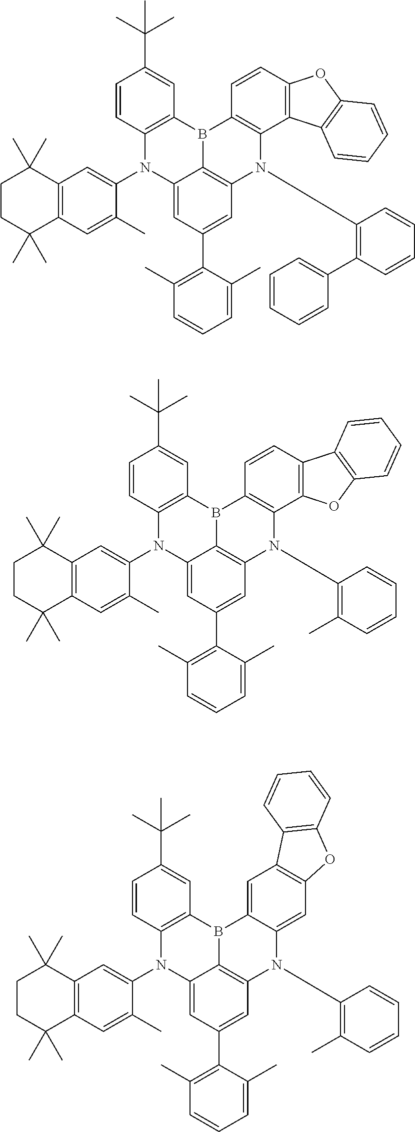 [SMILES: Cc1cc2c(cc1N1c3ccc(C(C)(C)C)cc3B3c4ccc5oc6ccccc6c5c4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccccc65)c4N(c4ccccc4C)c4cc(-c5c(C)cccc5C)cc1c43)C(C)(C)CCC2(C)C ; Cc1ccccc1N1c2cc3oc4ccccc4c3cc2B2c3cc(C(C)(C)C)ccc3N(c3cc4c(cc3C)C(C)(C)CCC4(C)C)c3cc(-c4c(C)cccc4C)cc1c32]

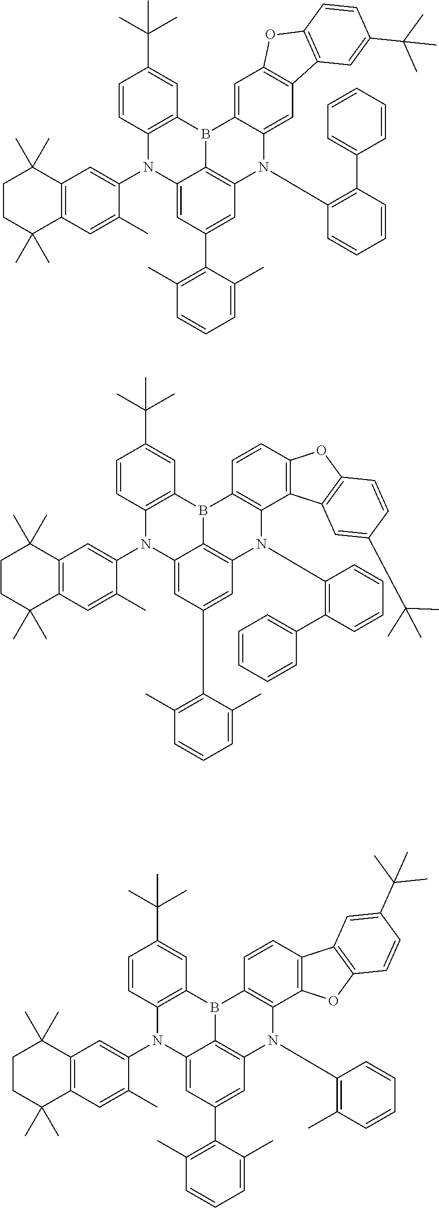 [SMILES: Cc1cc2c(cc1N1c3ccc(C(C)(C)C)cc3B3c4cc5oc6ccc(C(C)(C)C)cc6c5cc4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5oc6ccc(C(C)(C)C)cc6c5c4N(c4ccccc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(oc6ccc(C(C)(C)C)cc65)c4N(c4ccccc4C)c4cc(-c5c(C)cccc5C)cc1c43)C(C)(C)CCC2(C)C]

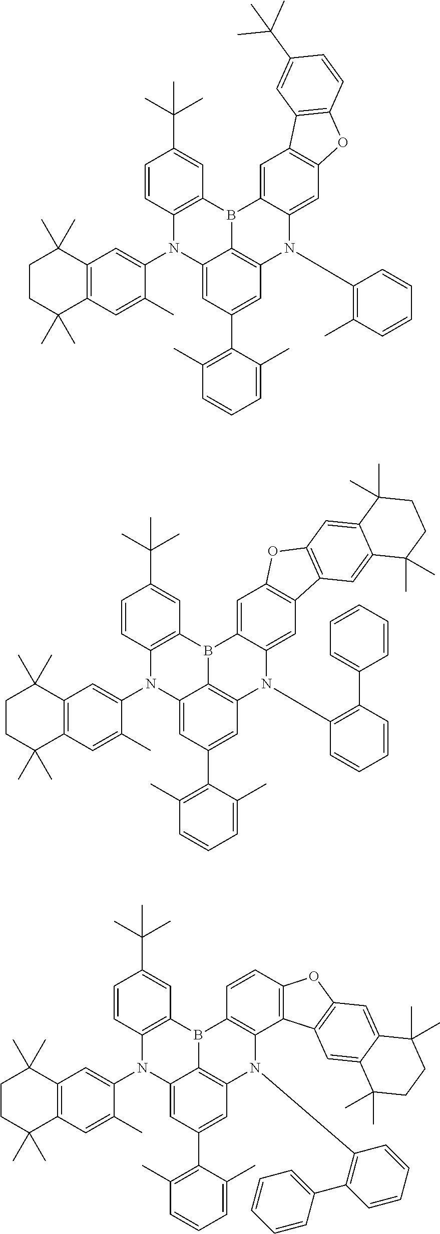 [SMILES: Cc1ccccc1N1c2cc3oc4ccc(C(C)(C)C)cc4c3cc2B2c3cc(C(C)(C)C)ccc3N(c3cc4c(cc3C)C(C)(C)CCC4(C)C)c3cc(-c4c(C)cccc4C)cc1c32 ; Cc1cc2c(cc1N1c3ccc(C(C)(C)C)cc3B3c4cc5oc6cc7c(cc6c5cc4N(c4ccccc4-c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5oc6cc7c(cc6c5c4N(c4ccccc4-c4ccccc4)c4cc(-c5c(C)cccc5C)cc1c43)C(C)(C)CCC7(C)C)C(C)(C)CCC2(C)C]

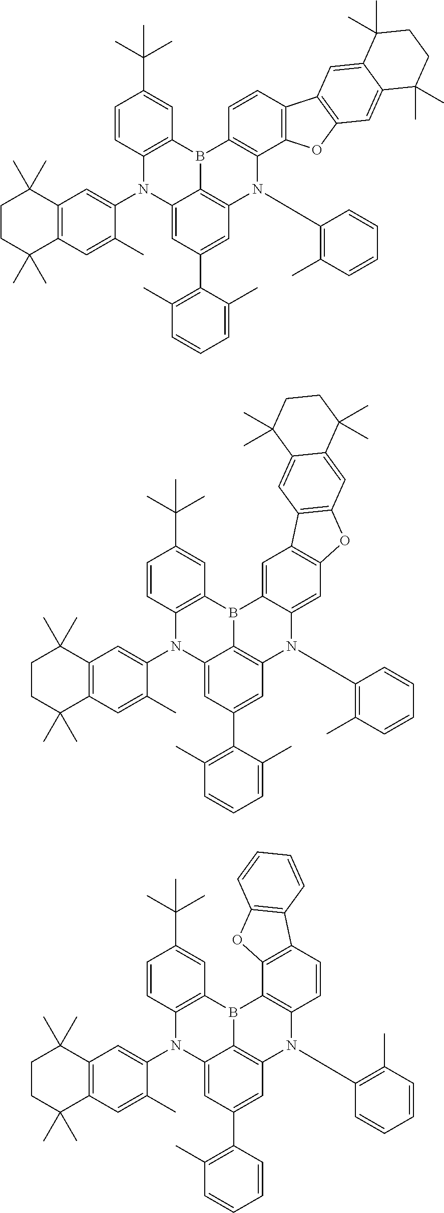

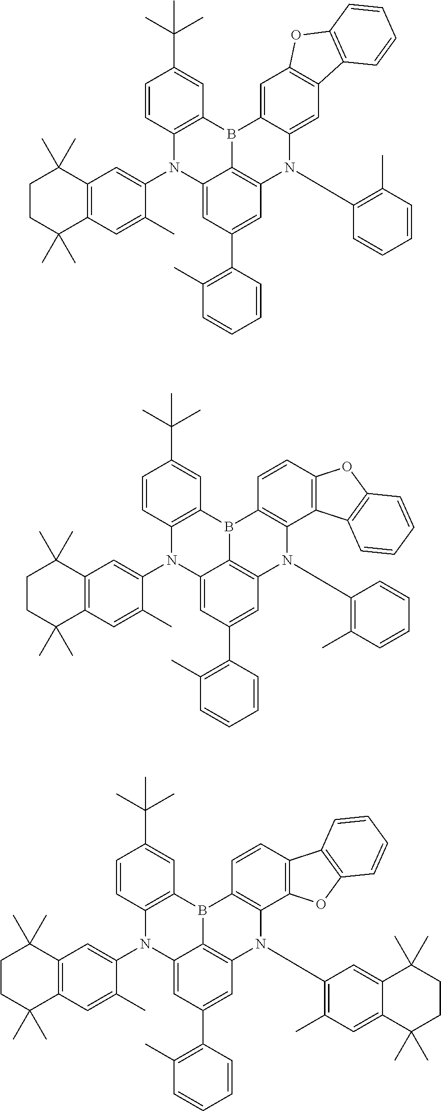 [SMILES: Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)oc1ccccc14 ; Cc1ccccc1-c1cc2c3c(c1)N(c1ccccc1C)c1c(ccc4oc5ccccc5c14)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1oc1ccccc14)B3c1cc(C(C)(C)C)ccc1N2c1cc2c(cc1C)C(C)(C)CCC2(C)C]

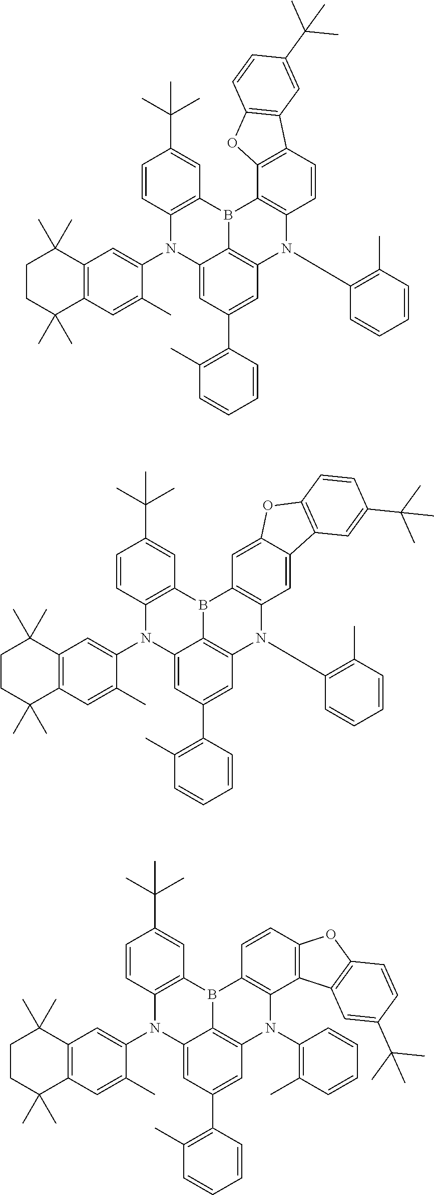 [SMILES: Cc1ccccc1-c1cc2c3c(c1)N(c1ccccc1C)c1ccc4c(oc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)oc1ccc(C(C)(C)C)cc14 ; Cc1ccccc1-c1cc2c3c(c1)N(c1ccccc1C)c1c(ccc4oc5ccc(C(C)(C)C)cc5c14)B3c1cc(C(C)(C)C)ccc1N2c1cc2c(cc1C)C(C)(C)CCC2(C)C]

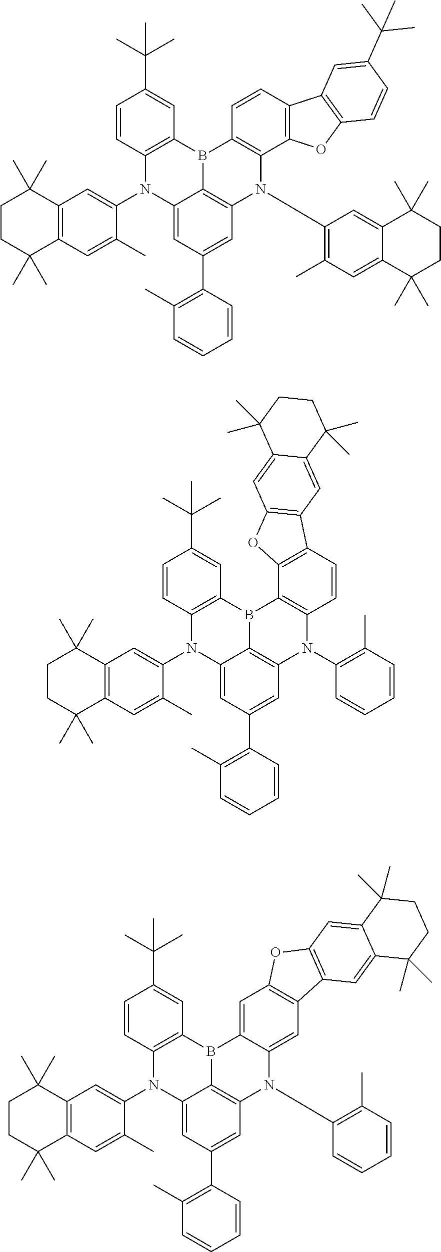 [SMILES: Cc1ccccc1-c1cc2c3c(c1)N(c1cc4c(cc1C)C(C)(C)CCC4(C)C)c1c(ccc4c1oc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccccc1C)c1ccc4c(oc5cc6c(cc54)C(C)(C)CCC6(C)C)c1B3c1cc(C(C)(C)C)ccc1N2c1cc2c(cc1C)C(C)(C)CCC2(C)C ; Cc1ccccc1-c1cc2c3c(c1)N(c1ccccc1C)c1cc4c(cc1B3c1cc(C(C)(C)C)ccc1N2c1cc2c(cc1C)C(C)(C)CCC2(C)C)oc1cc2c(cc14)C(C)(C)CCC2(C)C]

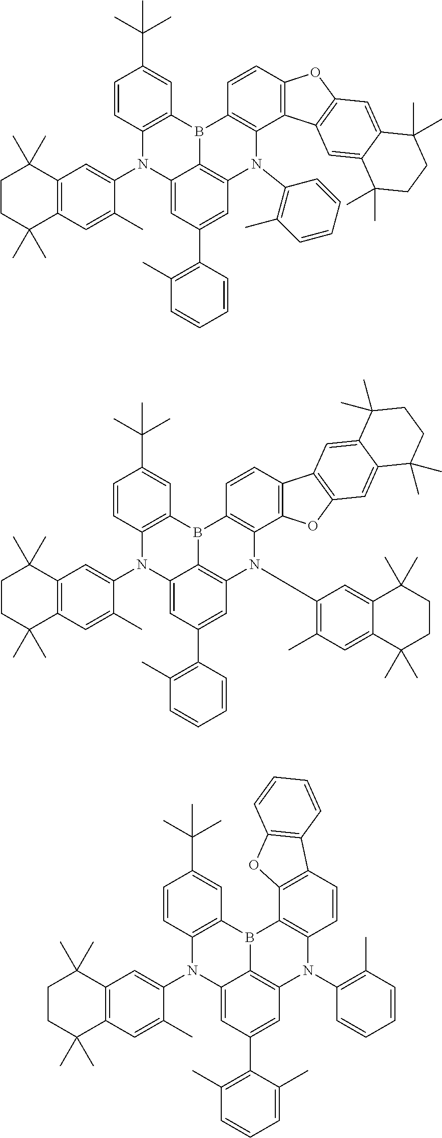 [SMILES: Cc1ccccc1-c1cc2c3c(c1)N(c1ccccc1C)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1c(ccc4c1oc1cc5c(cc14)C(C)(C)CCC5(C)C)B3c1cc(C(C)(C)C)ccc1N2c1cc2c(cc1C)C(C)(C)CCC2(C)C ; Cc1cc2c(cc1N1c3ccc(C(C)(C)C)cc3B3c4c1cc(-c1c(C)cccc1C)cc4N(c1ccccc1C)c1ccc4c(oc5ccccc54)c13)C(C)(C)CCC2(C)C]

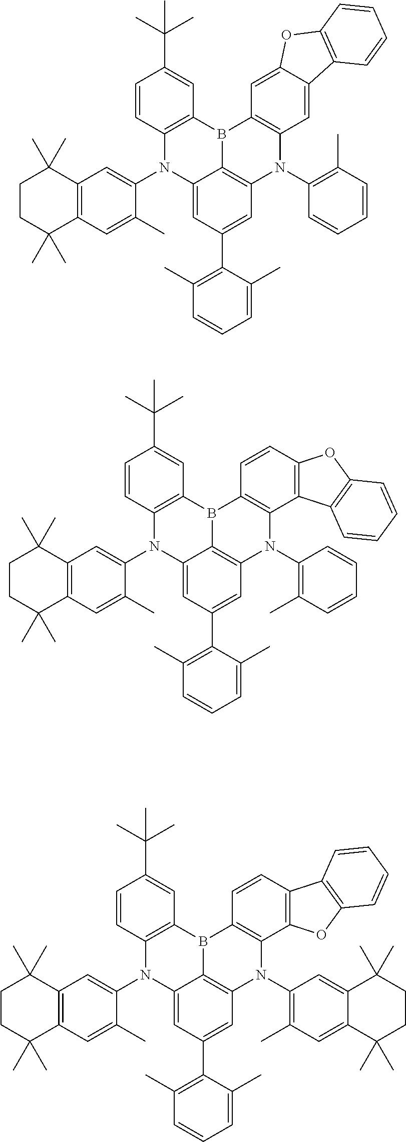 [SMILES: Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)oc1ccccc13 ; Cc1cc2c(cc1N1c3ccc(C(C)(C)C)cc3B3c4ccc5oc6ccccc6c5c4N(c4ccccc4C)c4cc(-c5c(C)cccc5C)cc1c43)C(C)(C)CCC2(C)C ; Cc1cc2c(cc1N1c3ccc(C(C)(C)C)cc3B3c4ccc5c(oc6ccccc65)c4N(c4cc5c(cc4C)C(C)(C)CCC5(C)C)c4cc(-c5c(C)cccc5C)cc1c43)C(C)(C)CCC2(C)C]

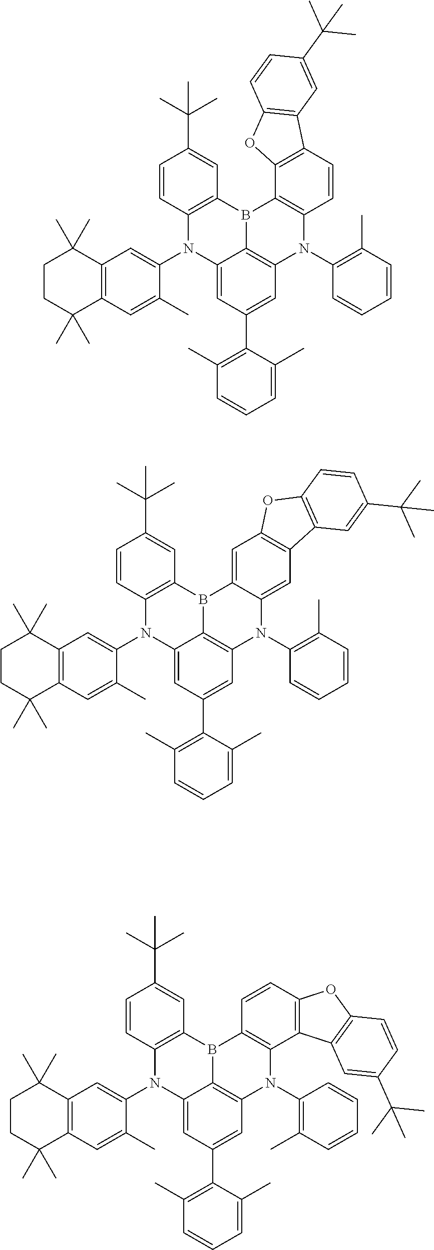 [SMILES: Cc1cc2c(cc1N1c3ccc(C(C)(C)C)cc3B3c4c1cc(-c1c(C)cccc1C)cc4N(c1ccccc1C)c1ccc4c(oc5ccc(C(C)(C)C)cc54)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)oc1ccc(C(C)(C)C)cc13 ; Cc1cc2c(cc1N1c3ccc(C(C)(C)C)cc3B3c4ccc5oc6ccc(C(C)(C)C)cc6c5c4N(c4ccccc4C)c4cc(-c5c(C)cccc5C)cc1c43)C(C)(C)CCC2(C)C]

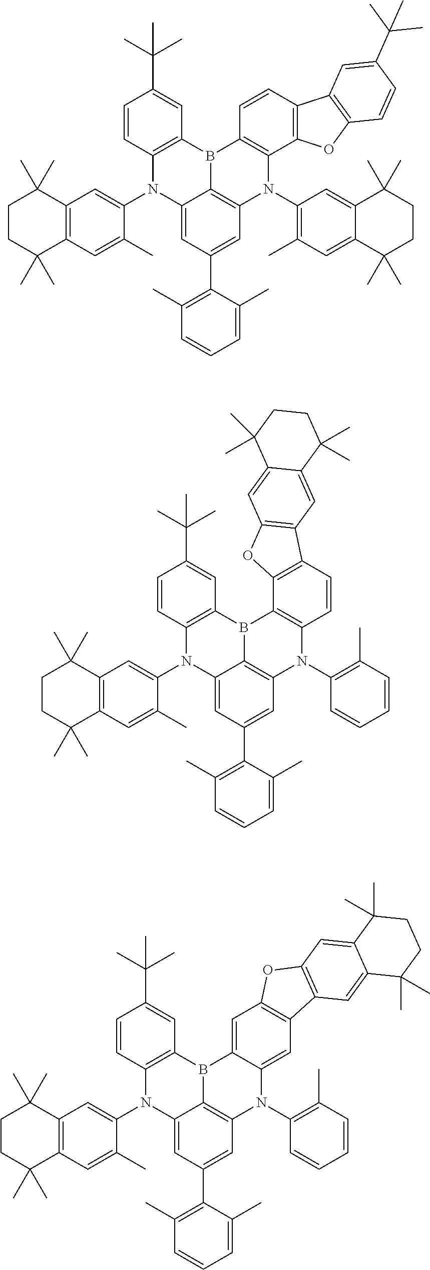 [SMILES: Cc1cc2c(cc1N1c3ccc(C(C)(C)C)cc3B3c4ccc5c(oc6ccc(C(C)(C)C)cc65)c4N(c4cc5c(cc4C)C(C)(C)CCC5(C)C)c4cc(-c5c(C)cccc5C)cc1c43)C(C)(C)CCC2(C)C ; Cc1cc2c(cc1N1c3ccc(C(C)(C)C)cc3B3c4c1cc(-c1c(C)cccc1C)cc4N(c1ccccc1C)c1ccc4c(oc5cc6c(cc54)C(C)(C)CCC6(C)C)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)oc1cc2c(cc13)C(C)(C)CCC2(C)C]

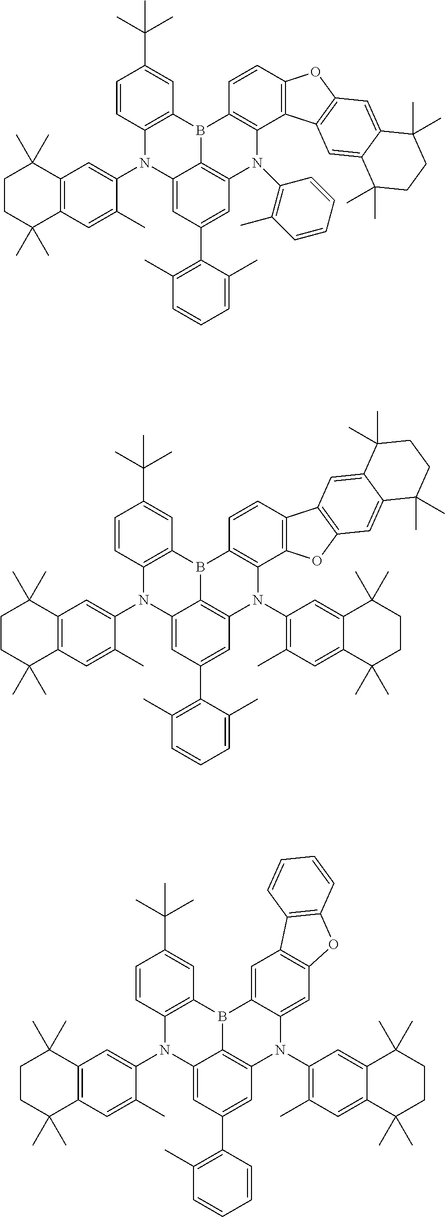 [SMILES: Cc1cc2c(cc1N1c3ccc(C(C)(C)C)cc3B3c4ccc5oc6cc7c(cc6c5c4N(c4ccccc4C)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5c(oc6cc7c(cc65)C(C)(C)CCC7(C)C)c4N(c4cc5c(cc4C)C(C)(C)CCC5(C)C)c4cc(-c5c(C)cccc5C)cc1c43)C(C)(C)CCC2(C)C ; Cc1ccccc1-c1cc2c3c(c1)N(c1cc4c(cc1C)C(C)(C)CCC4(C)C)c1cc4oc5ccccc5c4cc1B3c1cc(C(C)(C)C)ccc1N2c1cc2c(cc1C)C(C)(C)CCC2(C)C]

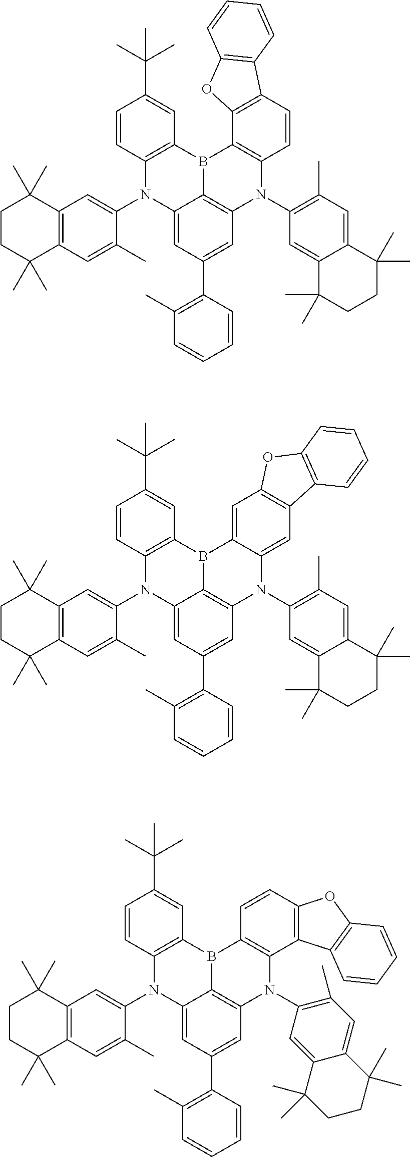 [SMILES: Cc1ccccc1-c1cc2c3c(c1)N(c1cc4c(cc1C)C(C)(C)CCC4(C)C)c1ccc4c(oc5ccccc54)c1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1ccccc14 ; Cc1ccccc1-c1cc2c3c(c1)N(c1cc4c(cc1C)C(C)(C)CCC4(C)C)c1c(ccc4oc5ccccc5c14)B3c1cc(C(C)(C)C)ccc1N2c1cc2c(cc1C)C(C)(C)CCC2(C)C]

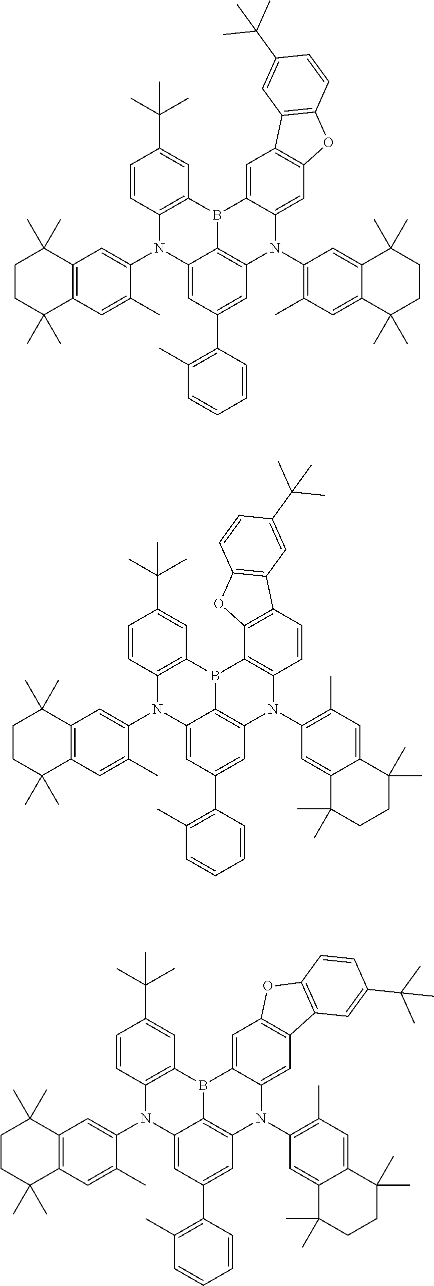 [SMILES: Cc1ccccc1-c1cc2c3c(c1)N(c1cc4c(cc1C)C(C)(C)CCC4(C)C)c1cc4oc5ccc(C(C)(C)C)cc5c4cc1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1ccc4c(oc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1ccc(C(C)(C)C)cc14]

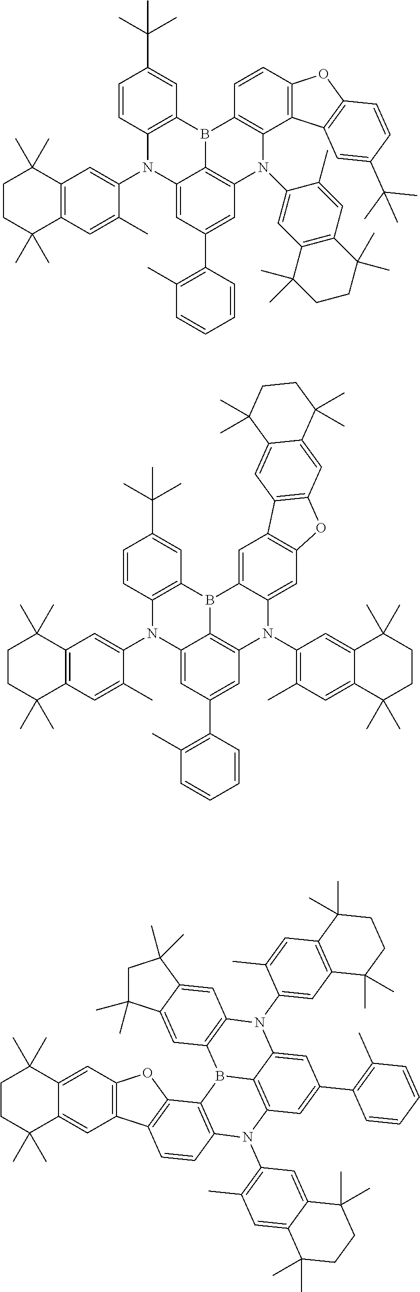 [SMILES: Cc1ccccc1-c1cc2c3c(c1)N(c1cc4c(cc1C)C(C)(C)CCC4(C)C)c1c(ccc4oc5ccc(C(C)(C)C)cc5c14)B3c1cc(C(C)(C)C)ccc1N2c1cc2c(cc1C)C(C)(C)CCC2(C)C ; Cc1ccccc1-c1cc2c3c(c1)N(c1cc4c(cc1C)C(C)(C)CCC4(C)C)c1cc4oc5cc6c(cc5c4cc1B3c1cc(C(C)(C)C)ccc1N2c1cc2c(cc1C)C(C)(C)CCC2(C)C)C(C)(C)CCC6(C)C ; Cc1ccccc1-c1cc2c3c(c1)N(c1cc4c(cc1C)C(C)(C)CCC4(C)C)c1ccc4c(oc5cc6c(cc54)C(C)(C)CCC6(C)C)c1B3c1cc3c(cc1N2c1cc2c(cc1C)C(C)(C)CCC2(C)C)C(C)(C)CC3(C)C]

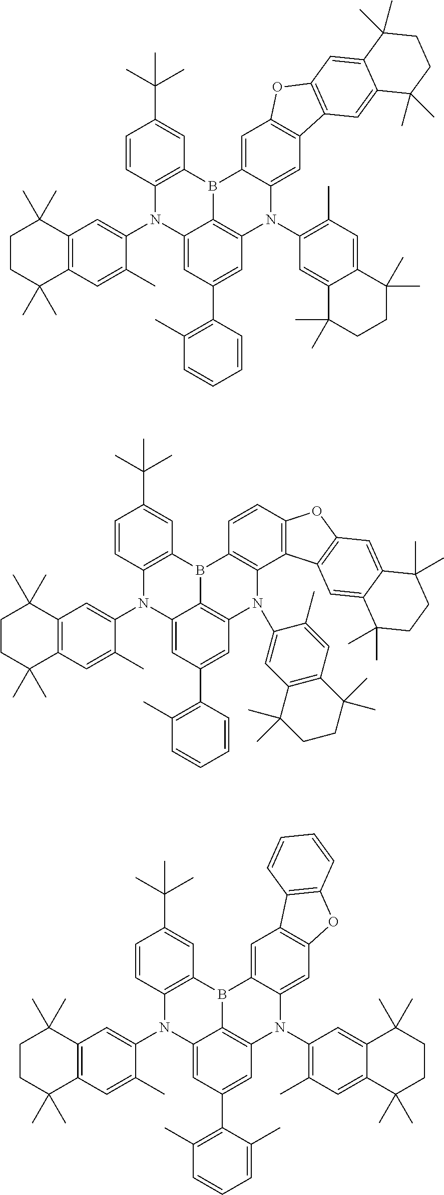 [SMILES: Cc1ccccc1-c1cc2c3c(c1)N(c1cc4c(cc1C)C(C)(C)CCC4(C)C)c1cc4c(cc1B3c1cc(C(C)(C)C)ccc1N2c1cc2c(cc1C)C(C)(C)CCC2(C)C)oc1cc2c(cc14)C(C)(C)CCC2(C)C ; Cc1ccccc1-c1cc2c3c(c1)N(c1cc4c(cc1C)C(C)(C)CCC4(C)C)c1c(ccc4oc5cc6c(cc5c14)C(C)(C)CCC6(C)C)B3c1cc(C(C)(C)C)ccc1N2c1cc2c(cc1C)C(C)(C)CCC2(C)C ; Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)oc1ccccc15)C(C)(C)CCC2(C)C]

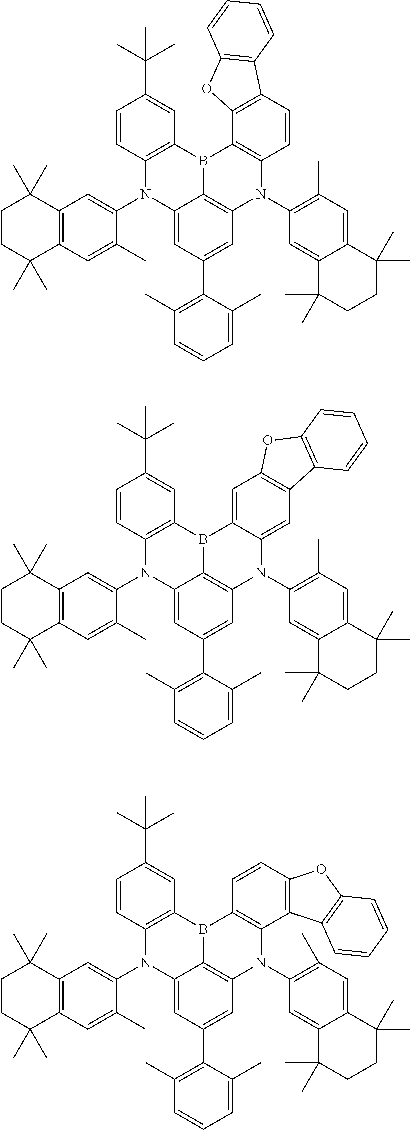 [SMILES: Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(oc5ccccc54)c13)C(C)(C)CCC2(C)C ; Cc1cc2c(cc1N1c3ccc(C(C)(C)C)cc3B3c4cc5oc6ccccc6c5cc4N(c4cc5c(cc4C)C(C)(C)CCC5(C)C)c4cc(-c5c(C)cccc5C)cc1c43)C(C)(C)CCC2(C)C ; Cc1cc2c(cc1N1c3ccc(C(C)(C)C)cc3B3c4ccc5oc6ccccc6c5c4N(c4cc5c(cc4C)C(C)(C)CCC5(C)C)c4cc(-c5c(C)cccc5C)cc1c43)C(C)(C)CCC2(C)C]

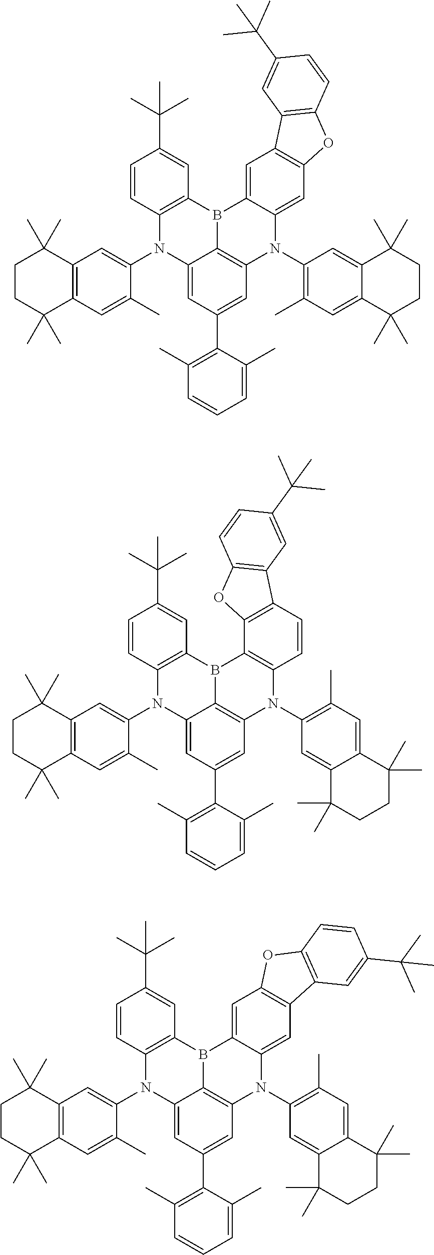 [SMILES: Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)oc1ccc(C(C)(C)C)cc15)C(C)(C)CCC2(C)C ; Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(oc5ccc(C(C)(C)C)cc54)c13)C(C)(C)CCC2(C)C ; Cc1cc2c(cc1N1c3ccc(C(C)(C)C)cc3B3c4cc5oc6ccc(C(C)(C)C)cc6c5cc4N(c4cc5c(cc4C)C(C)(C)CCC5(C)C)c4cc(-c5c(C)cccc5C)cc1c43)C(C)(C)CCC2(C)C]

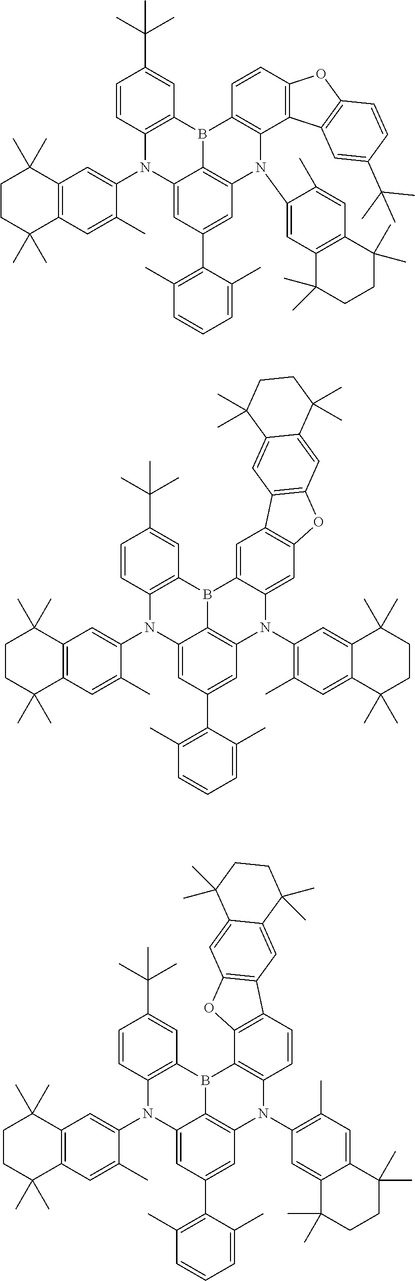 [SMILES: Cc1cc2c(cc1N1c3ccc(C(C)(C)C)cc3B3c4ccc5oc6ccc(C(C)(C)C)cc6c5c4N(c4cc5c(cc4C)C(C)(C)CCC5(C)C)c4cc(-c5c(C)cccc5C)cc1c43)C(C)(C)CCC2(C)C ; Cc1cc2c(cc1N1c3ccc(C(C)(C)C)cc3B3c4cc5c(cc4N(c4cc6c(cc4C)C(C)(C)CCC6(C)C)c4cc(-c6c(C)cccc6C)cc1c43)oc1cc3c(cc15)C(C)(C)CCC3(C)C)C(C)(C)CCC2(C)C ; Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(oc5cc6c(cc54)C(C)(C)CCC6(C)C)c13)C(C)(C)CCC2(C)C]

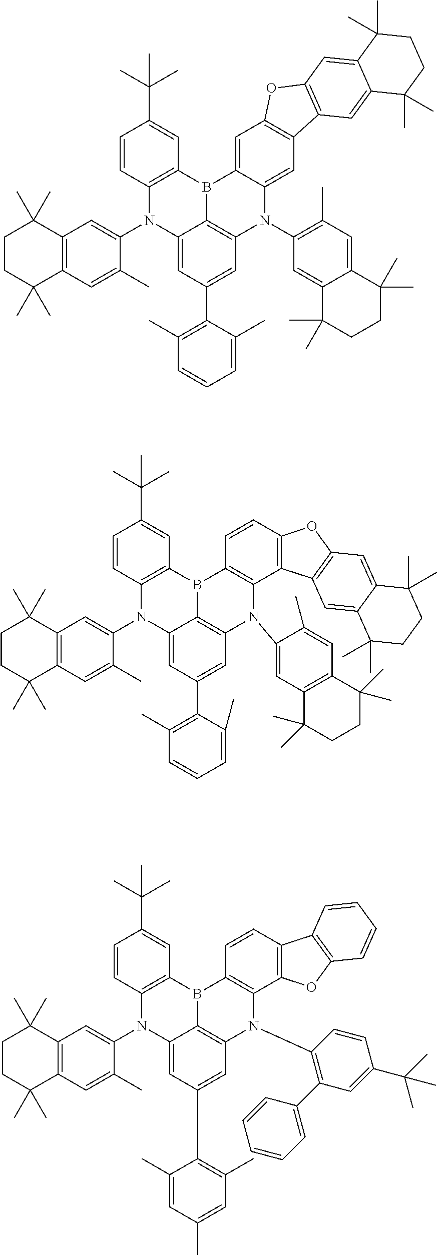 [SMILES: Cc1cc2c(cc1N1c3ccc(C(C)(C)C)cc3B3c4cc5oc6cc7c(cc6c5cc4N(c4cc5c(cc4C)C(C)(C)CCC5(C)C)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5oc6cc7c(cc6c5c4N(c4cc5c(cc4C)C(C)(C)CCC5(C)C)c4cc(-c5c(C)cccc5C)cc1c43)C(C)(C)CCC7(C)C)C(C)(C)CCC2(C)C ; Cc1cc(C)c(-c2cc3c4c(c2)N(c2ccc(C(C)(C)C)cc2-c2ccccc2)c2c(ccc5c2oc2ccccc25)B4c2cc(C(C)(C)C)ccc2N3c2cc3c(cc2C)C(C)(C)CCC3(C)C)c(C)c1]

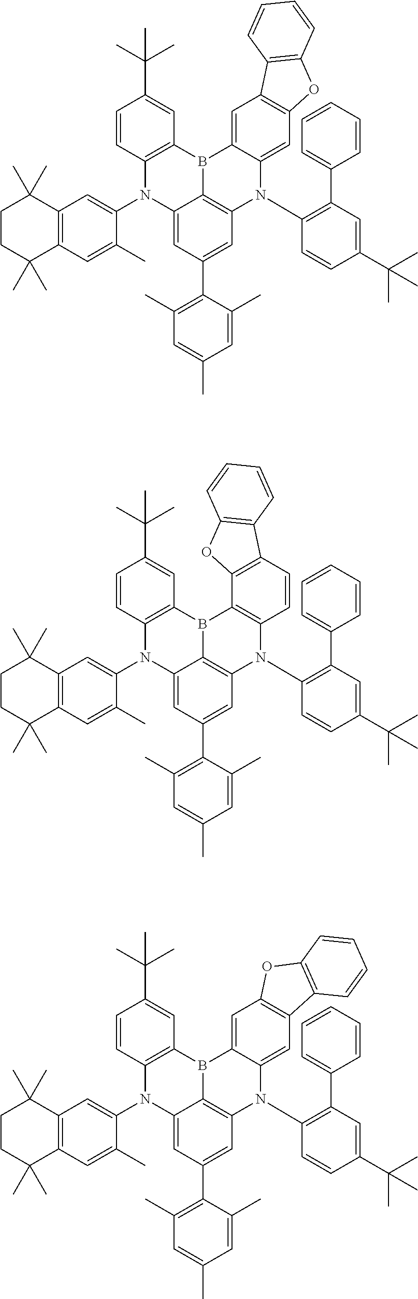 [SMILES: Cc1cc(C)c(-c2cc3c4c(c2)N(c2ccc(C(C)(C)C)cc2-c2ccccc2)c2cc5oc6ccccc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2ccc5c(oc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)oc2ccccc25)c(C)c1]

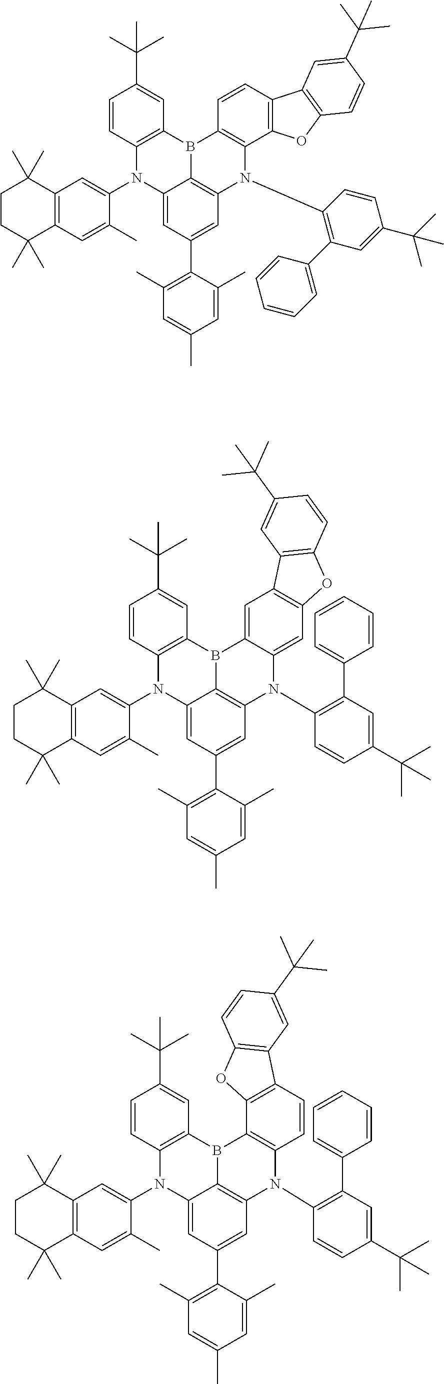 [SMILES: Cc1cc(C)c(-c2cc3c4c(c2)N(c2ccc(C(C)(C)C)cc2-c2ccccc2)c2c(ccc5c2oc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5oc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2ccc5c(oc6ccc(C(C)(C)C)cc65)c2B4c2cc(C(C)(C)C)ccc2N3c2cc3c(cc2C)C(C)(C)CCC3(C)C)c(C)c1]

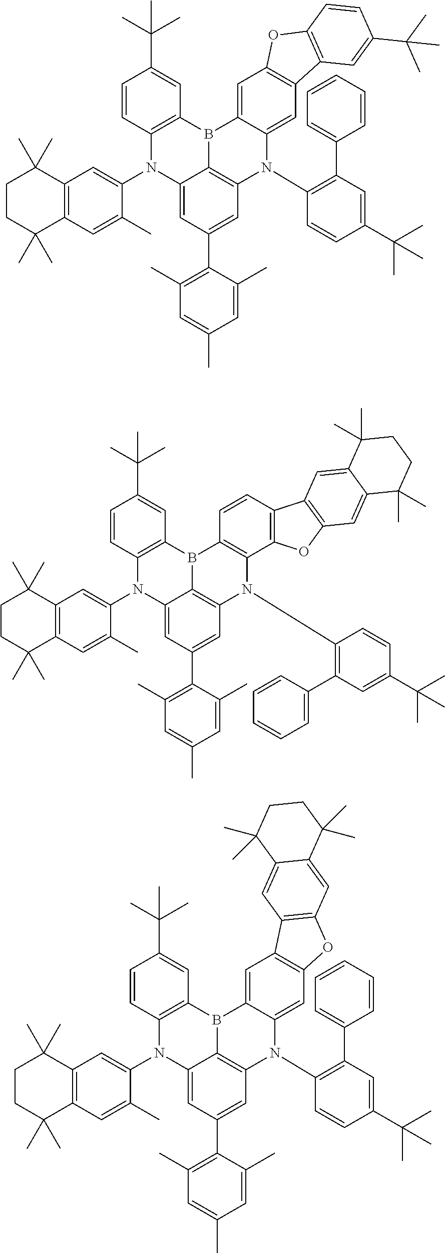 [SMILES: Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)oc2ccc(C(C)(C)C)cc25)c(C)c1 ; Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5oc6cc7c(cc6c5cc2B4c2cc(C(C)(C)C)ccc2N3c2cc3c(cc2C)C(C)(C)CCC3(C)C)C(C)(C)CCC7(C)C)c(C)c1]

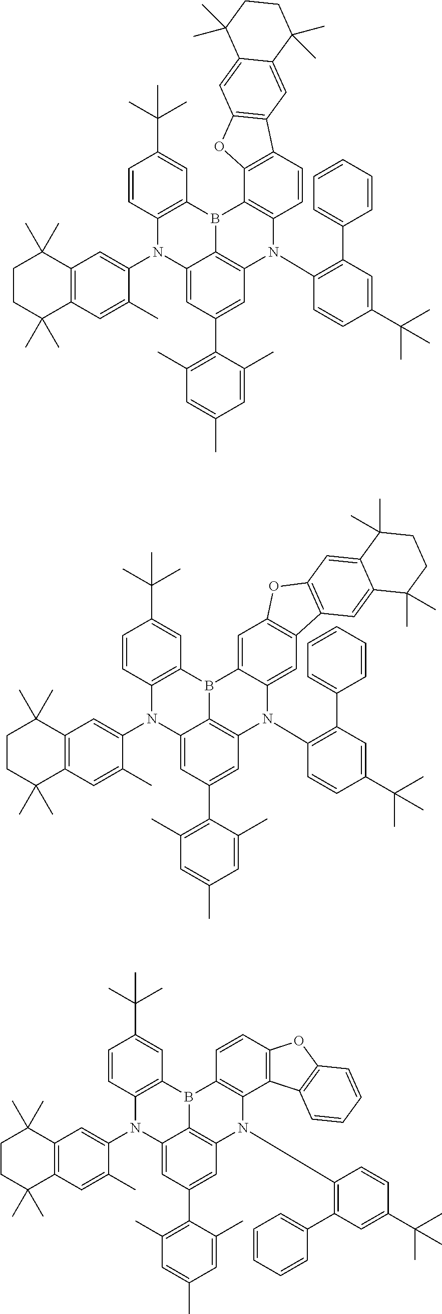 [SMILES: Cc1cc(C)c(-c2cc3c4c(c2)N(c2ccc(C(C)(C)C)cc2-c2ccccc2)c2ccc5c(oc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1 ; Cc1cc(C)c(-c2cc3c4c(c2)N(c2ccc(C(C)(C)C)cc2-c2ccccc2)c2c(ccc5oc6ccccc6c25)B4c2cc(C(C)(C)C)ccc2N3c2cc3c(cc2C)C(C)(C)CCC3(C)C)c(C)c1]

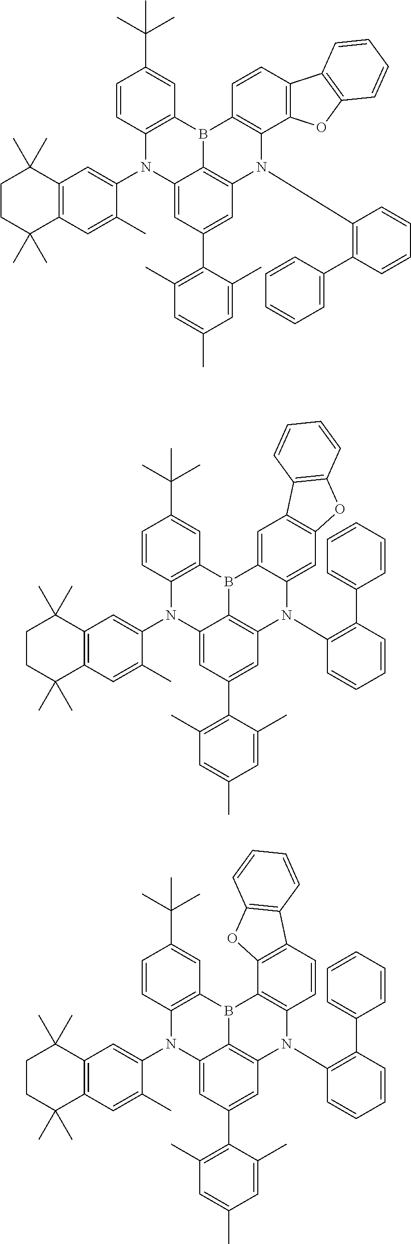

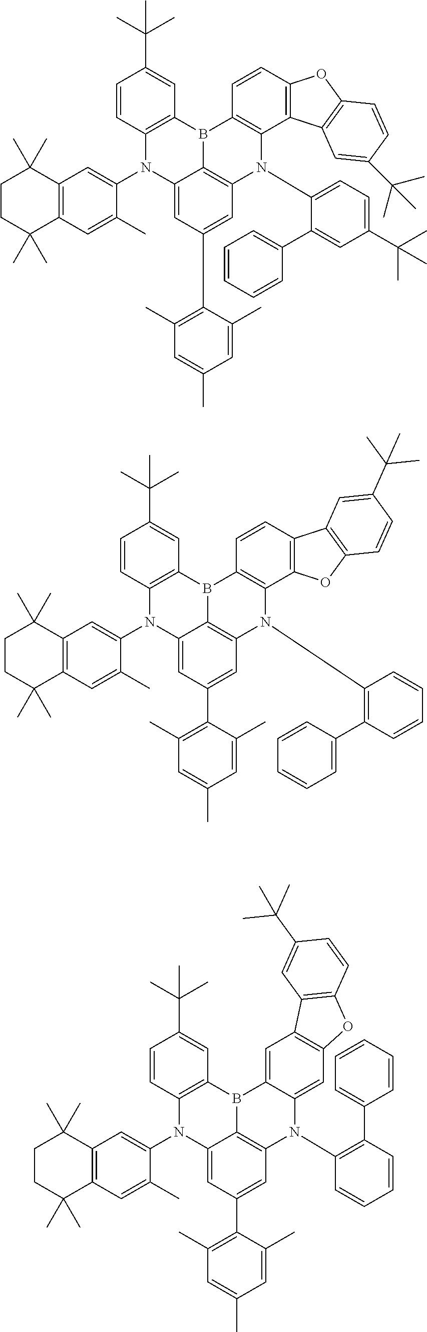 [SMILES: Cc1cc(C)c(-c2cc3c4c(c2)N(c2ccc(C(C)(C)C)cc2-c2ccccc2)c2c(ccc5oc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2oc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5oc6ccc(C(C)(C)C)cc6c5cc2B4c2cc(C(C)(C)C)ccc2N3c2cc3c(cc2C)C(C)(C)CCC3(C)C)c(C)c1]

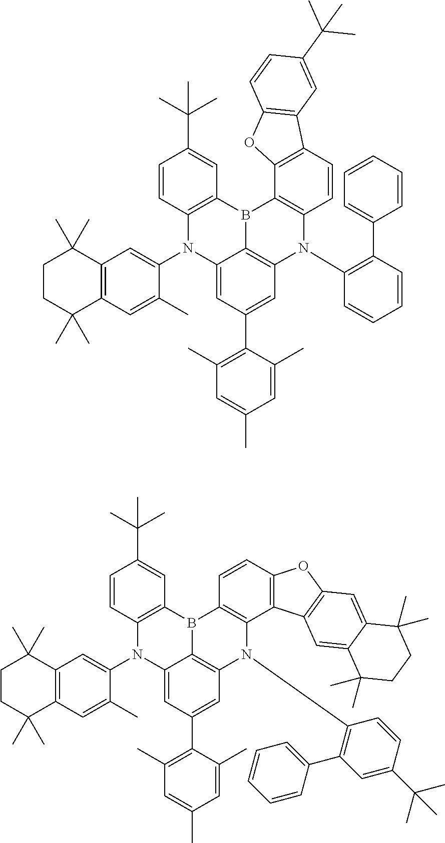 [SMILES: Cc1cc(C)c(-c2cc3c4c(c2)N(c2ccccc2-c2ccccc2)c2ccc5c(oc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1]

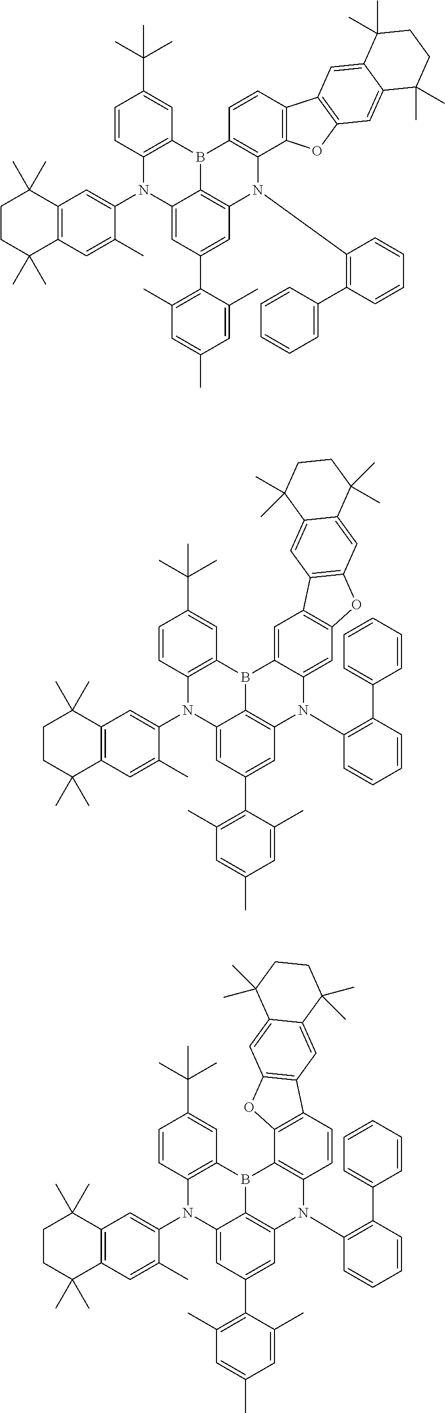 [SMILES: Cc1cc(C)c(-c2cc3c4c(c2)N(c2ccccc2-c2ccccc2)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5oc6cc7c(cc6c5cc2B4c2cc(C(C)(C)C)ccc2N3c2cc3c(cc2C)C(C)(C)CCC3(C)C)C(C)(C)CCC7(C)C)c(C)c1 ; Cc1cc(C)c(-c2cc3c4c(c2)N(c2ccccc2-c2ccccc2)c2ccc5c(oc6cc7c(cc65)C(C)(C)CCC7(C)C)c2B4c2cc(C(C)(C)C)ccc2N3c2cc3c(cc2C)C(C)(C)CCC3(C)C)c(C)c1]

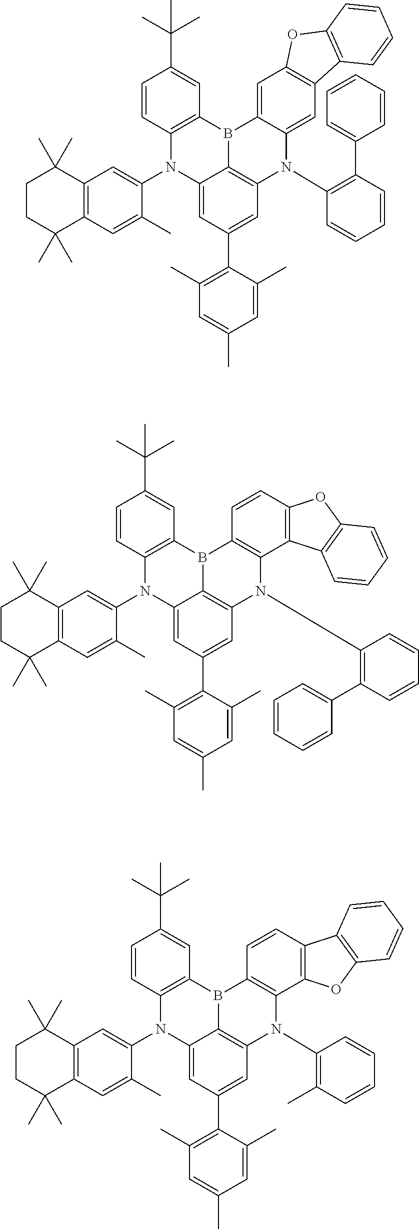 [SMILES: Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)oc2ccccc25)c(C)c1 ; Cc1cc(C)c(-c2cc3c4c(c2)N(c2ccccc2-c2ccccc2)c2c(ccc5oc6ccccc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2c(ccc5c2oc2ccccc25)B4c2cc(C(C)(C)C)ccc2N3c2cc3c(cc2C)C(C)(C)CCC3(C)C)c(C)c1]

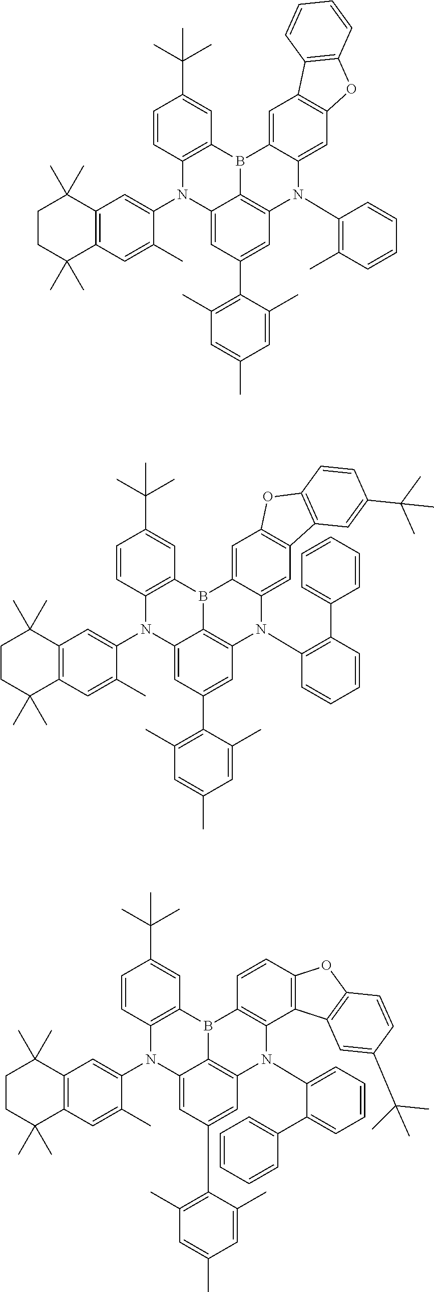 [SMILES: Cc1cc(C)c(-c2cc3c4c(c2)N(c2ccccc2C)c2cc5oc6ccccc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)oc2ccc(C(C)(C)C)cc25)c(C)c1 ; Cc1cc(C)c(-c2cc3c4c(c2)N(c2ccccc2-c2ccccc2)c2c(ccc5oc6ccc(C(C)(C)C)cc6c25)B4c2cc(C(C)(C)C)ccc2N3c2cc3c(cc2C)C(C)(C)CCC3(C)C)c(C)c1]

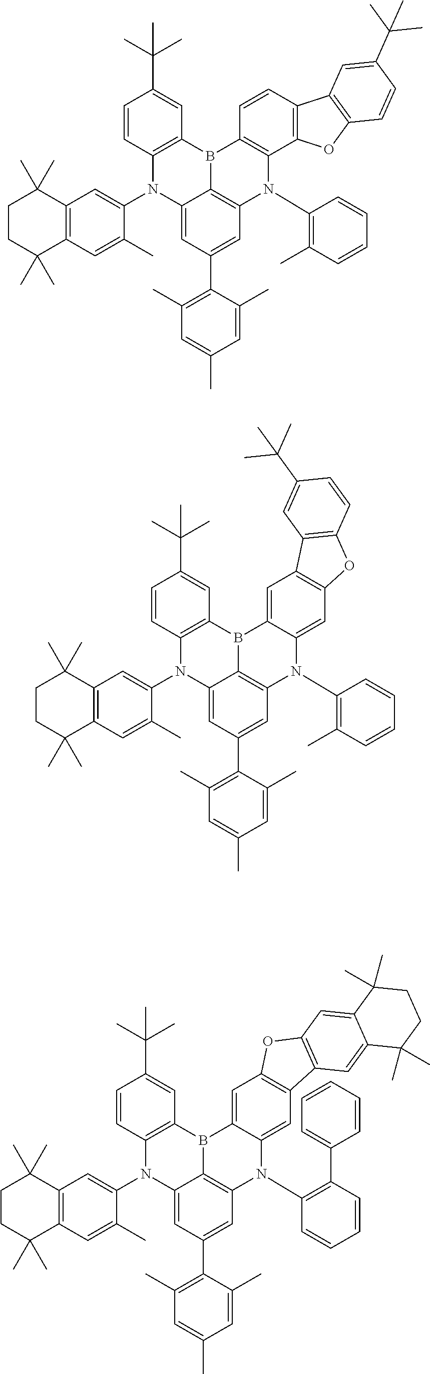 [SMILES: Cc1cc(C)c(-c2cc3c4c(c2)N(c2ccccc2C)c2c(ccc5c2oc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5oc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1]

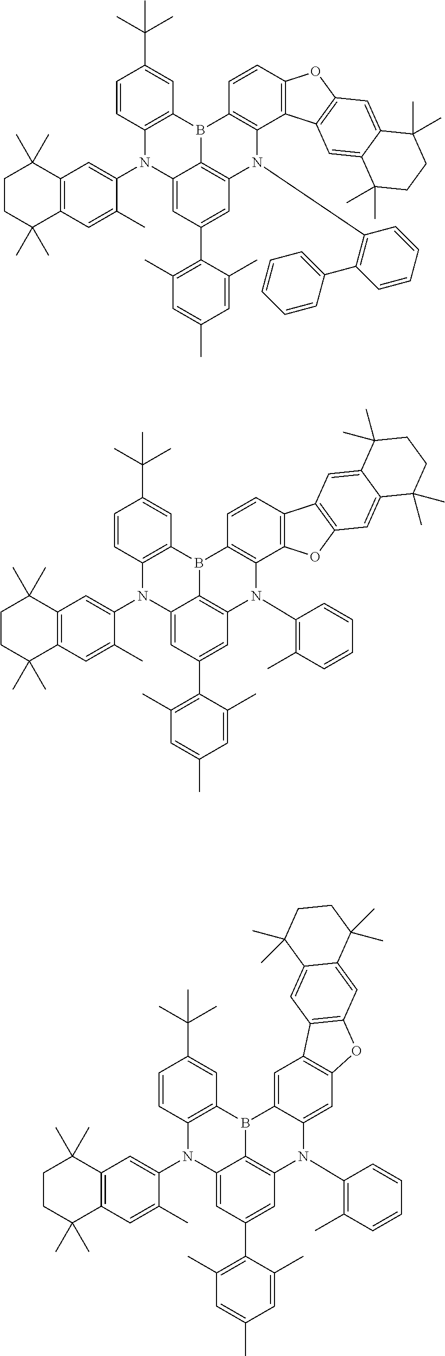 [SMILES: Cc1cc(C)c(-c2cc3c4c(c2)N(c2ccccc2-c2ccccc2)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5oc6cc7c(cc6c5cc2B4c2cc(C(C)(C)C)ccc2N3c2cc3c(cc2C)C(C)(C)CCC3(C)C)C(C)(C)CCC7(C)C)c(C)c1]

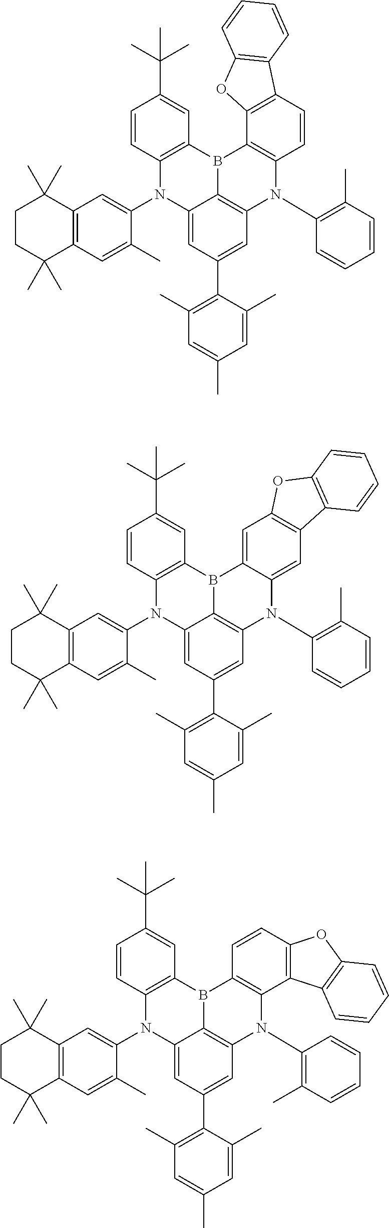 [SMILES: Cc1cc(C)c(-c2cc3c4c(c2)N(c2ccccc2C)c2ccc5c(oc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)oc2ccccc25)c(C)c1 ; Cc1cc(C)c(-c2cc3c4c(c2)N(c2ccccc2C)c2c(ccc5oc6ccccc6c25)B4c2cc(C(C)(C)C)ccc2N3c2cc3c(cc2C)C(C)(C)CCC3(C)C)c(C)c1]

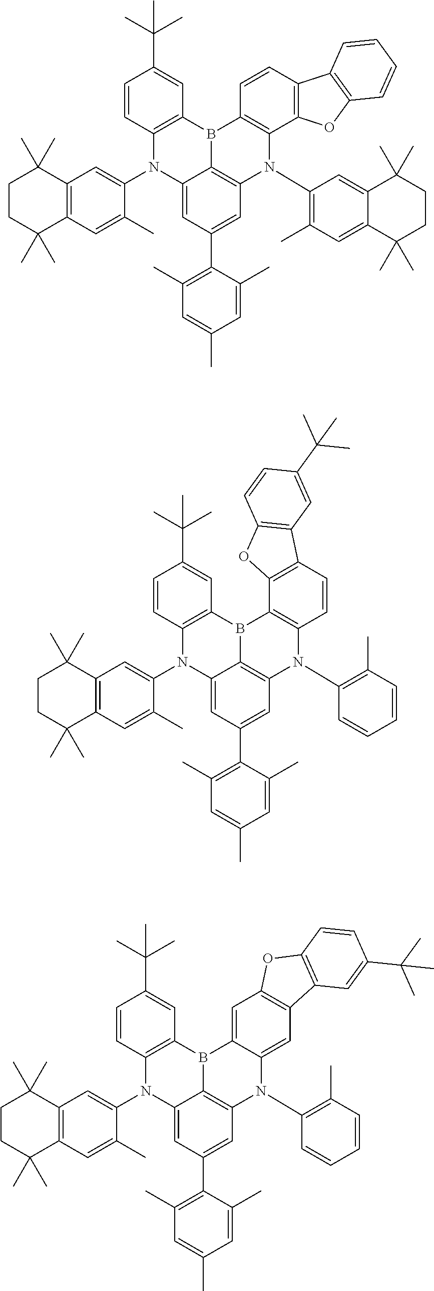 [SMILES: Cc1cc(C)c(-c2cc3c4c(c2)N(c2cc5c(cc2C)C(C)(C)CCC5(C)C)c2c(ccc5c2oc2ccccc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2ccc5c(oc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)oc2ccc(C(C)(C)C)cc25)c(C)c1]

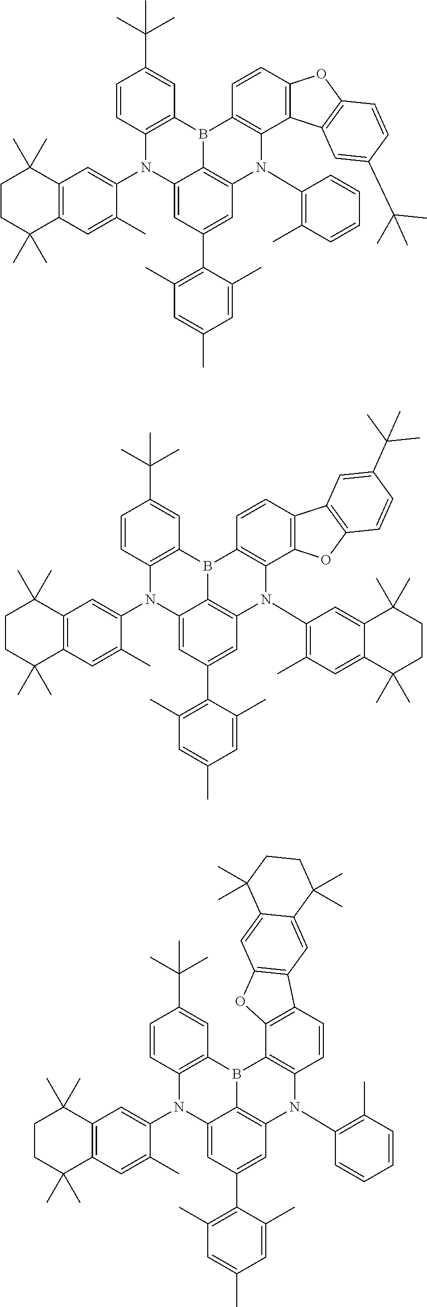 [SMILES: Cc1cc(C)c(-c2cc3c4c(c2)N(c2ccccc2C)c2c(ccc5oc6ccc(C(C)(C)C)cc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2oc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2ccc5c(oc6cc7c(cc65)C(C)(C)CCC7(C)C)c2B4c2cc(C(C)(C)C)ccc2N3c2cc3c(cc2C)C(C)(C)CCC3(C)C)c(C)c1]

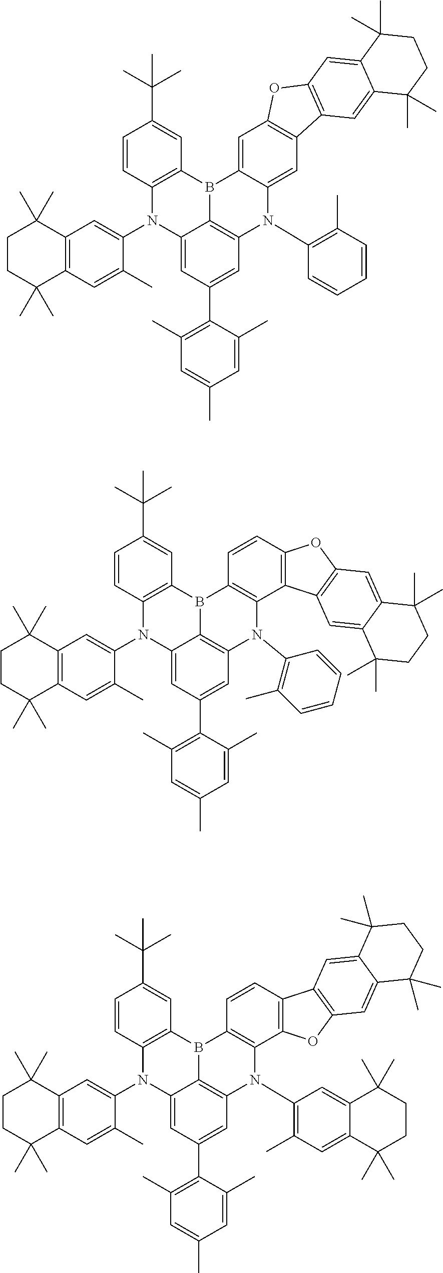 [SMILES: Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1 ; Cc1cc(C)c(-c2cc3c4c(c2)N(c2ccccc2C)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2oc2cc6c(cc25)C(C)(C)CCC6(C)C)B4c2cc(C(C)(C)C)ccc2N3c2cc3c(cc2C)C(C)(C)CCC3(C)C)c(C)c1]

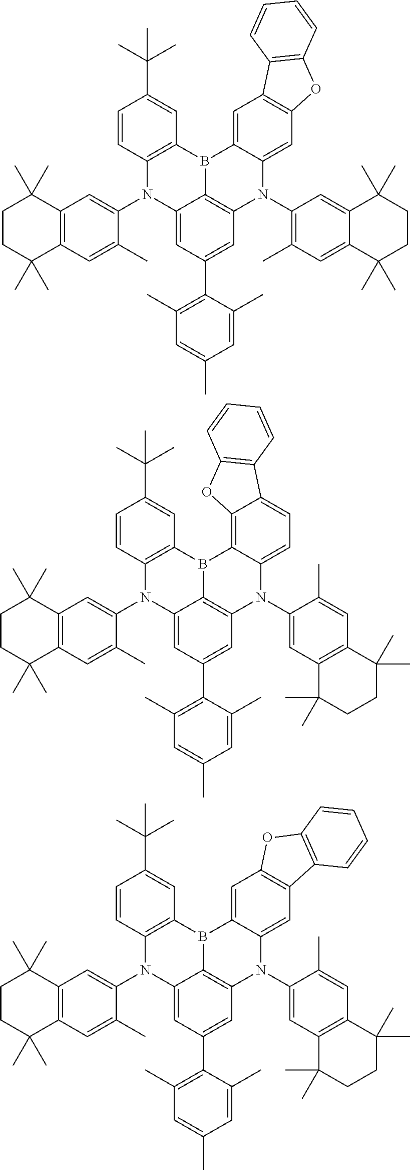

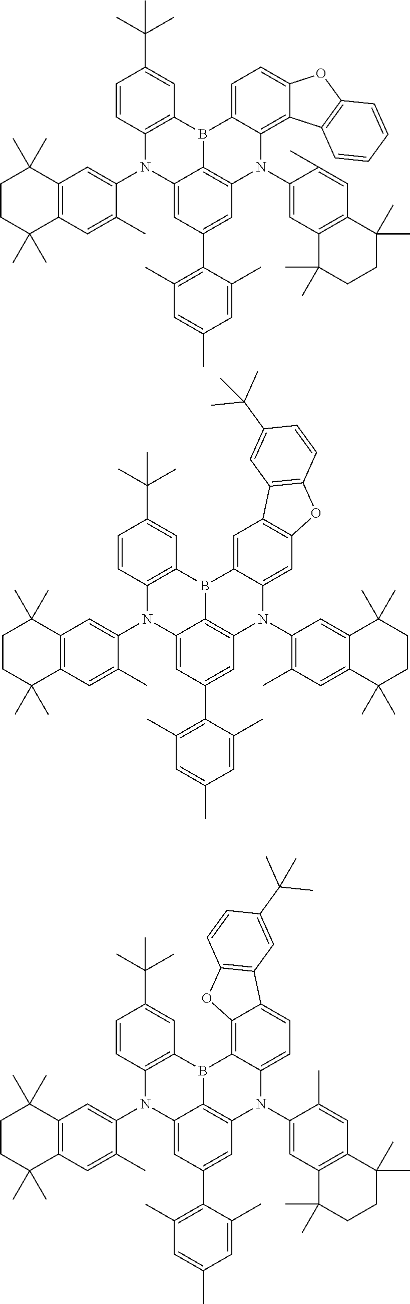

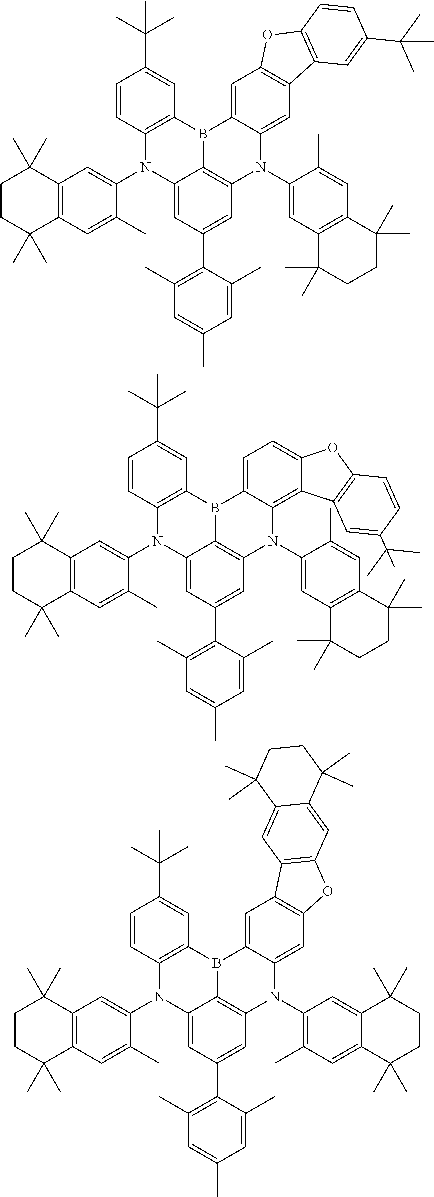

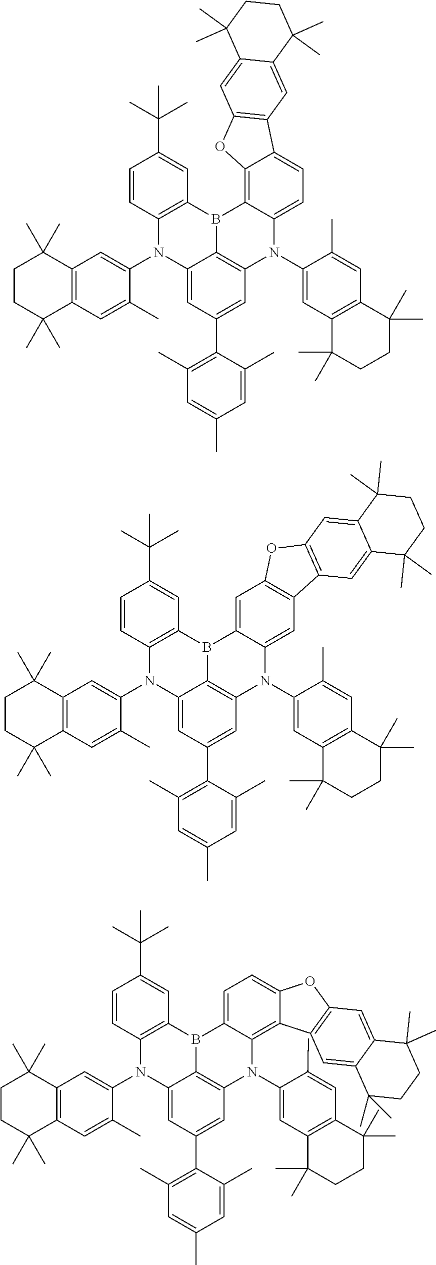 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2cc5c(cc2B4c2cc(C(C)(C)C)ccc2N3c2cc3c(cc2C)C(C)(C)CCC3(C)C)oc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5oc6cc7c(cc6c25)C(C)(C)CCC7(C)C)B4c2cc(C(C)(C)C)ccc2N3c2cc3c(cc2C)C(C)(C)CCC3(C)C)c(C)c1]

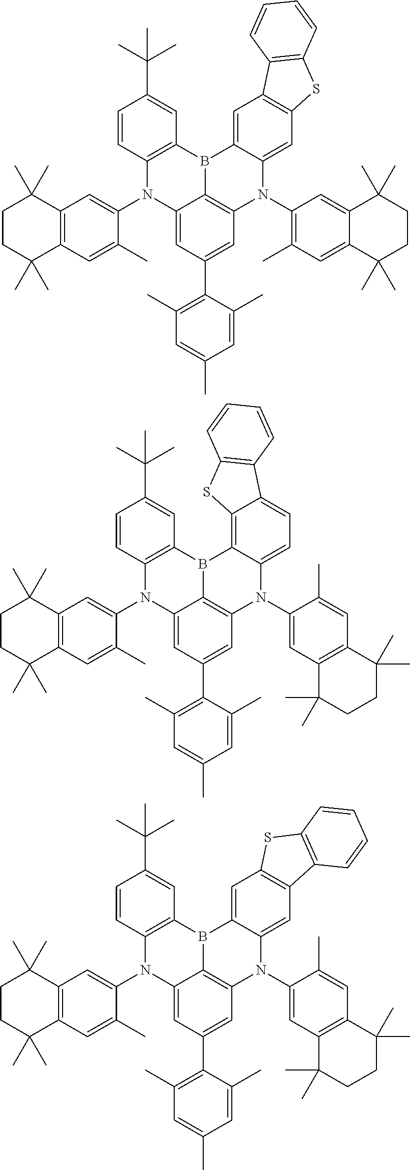

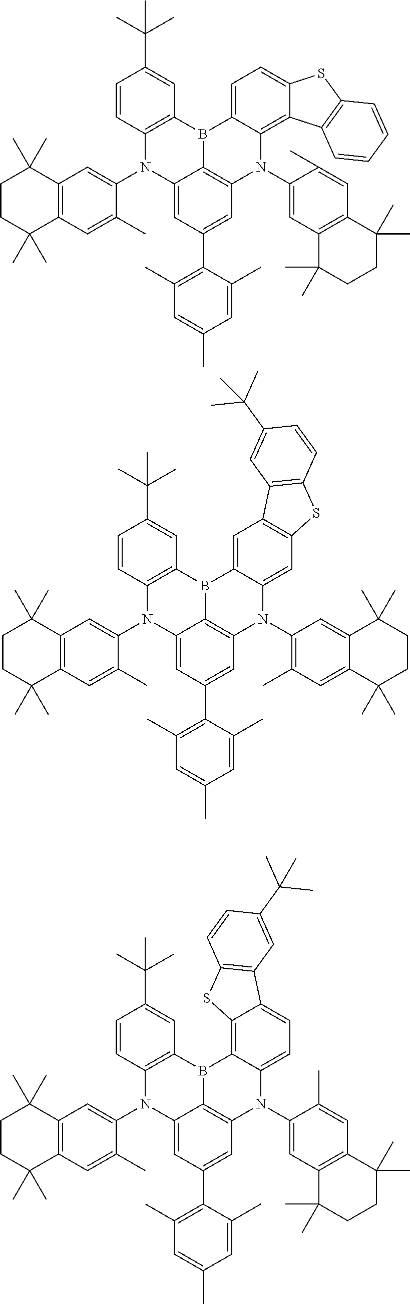

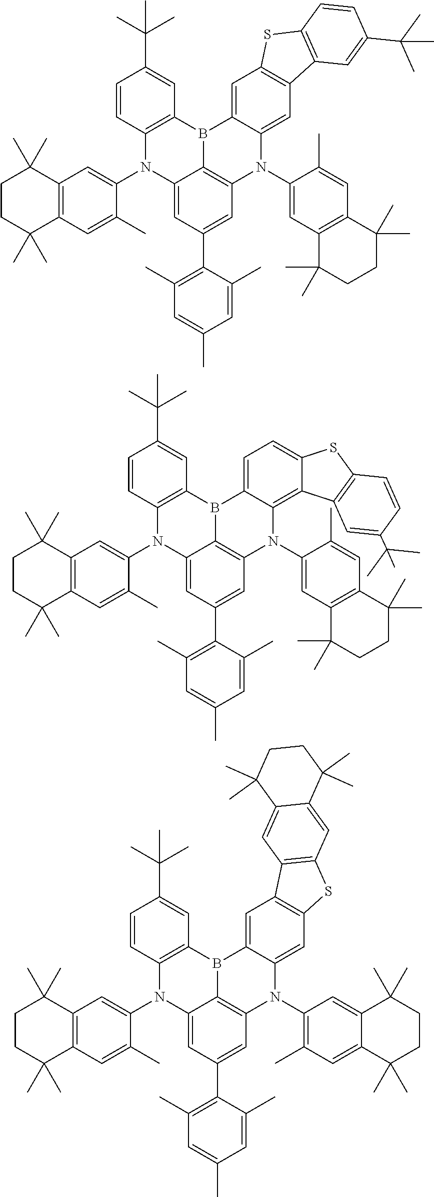

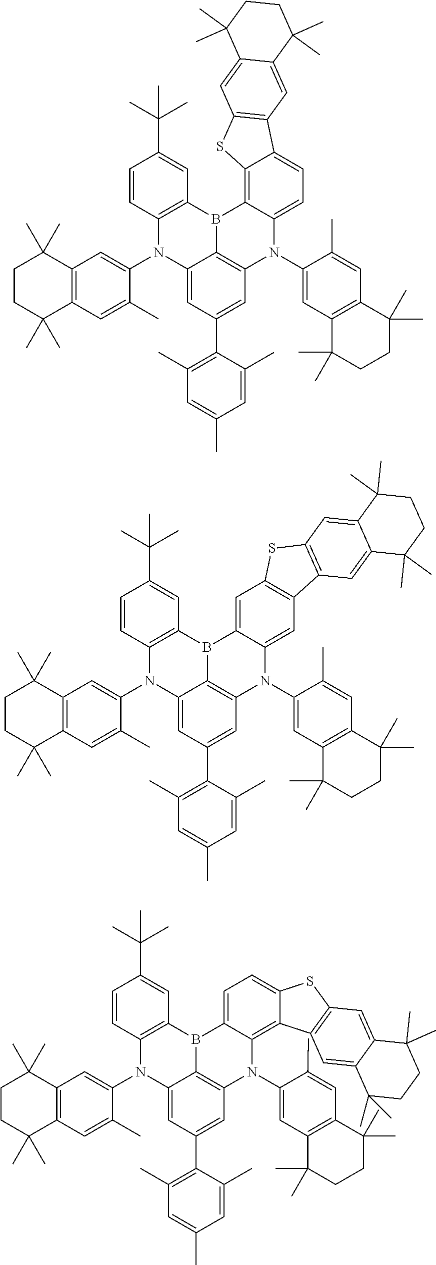 [SMILES: Cc1cc(C)c(-c2cc3c4c(c2)N(c2cc5c(cc2C)C(C)(C)CCC5(C)C)c2ccc5c(sc6cc7c(cc65)C(C)(C)CCC7(C)C)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2cc5c(cc2B4c2cc(C(C)(C)C)ccc2N3c2cc3c(cc2C)C(C)(C)CCC3(C)C)sc2cc3c(cc25)C(C)(C)CCC3(C)C)c(C)c1 ; Cc1cc(C)c(-c2cc3c4c(c2)N(c2cc5c(cc2C)C(C)(C)CCC5(C)C)c2c(ccc5sc6cc7c(cc6c25)C(C)(C)CCC7(C)C)B4c2cc(C(C)(C)C)ccc2N3c2cc3c(cc2C)C(C)(C)CCC3(C)C)c(C)c1]

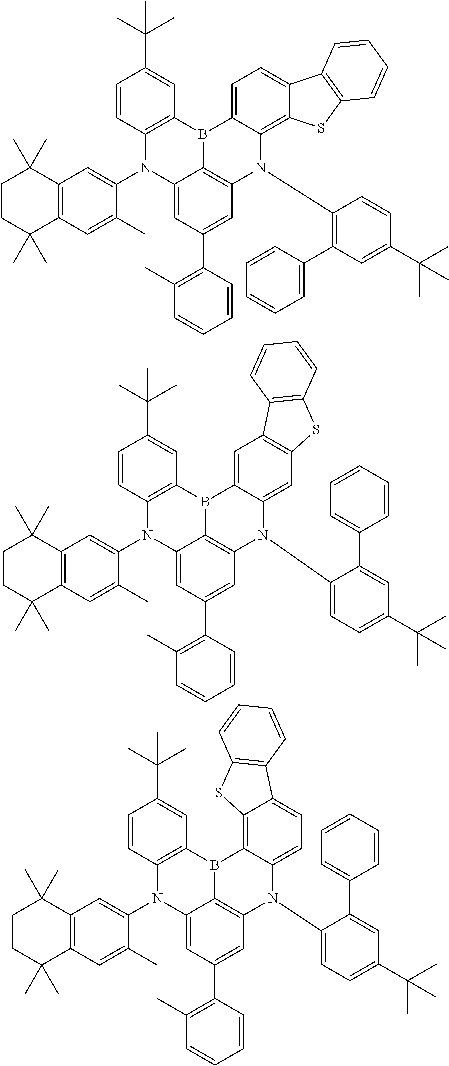

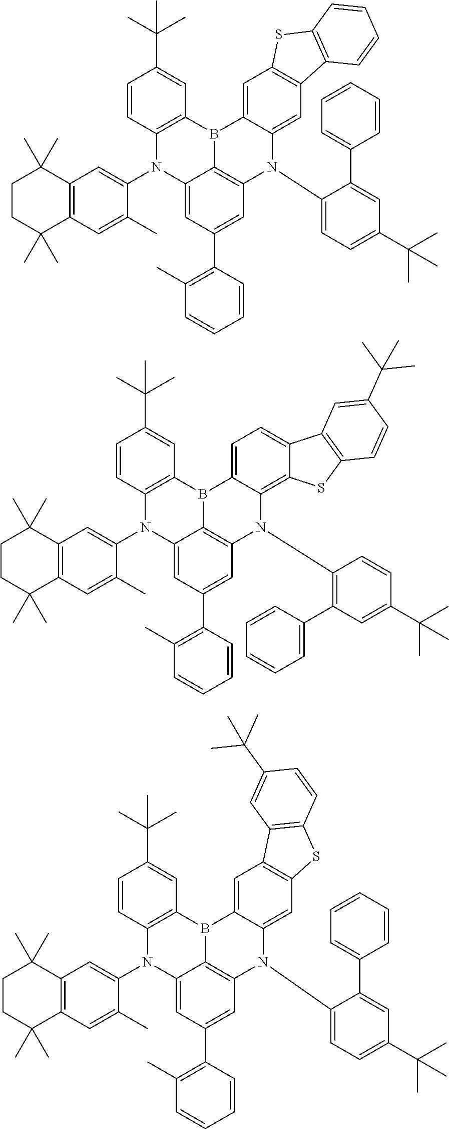

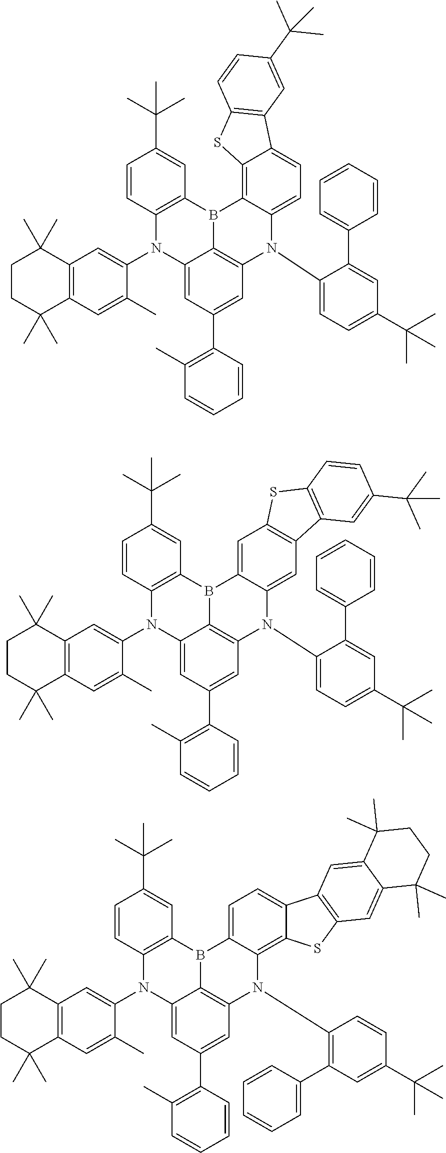 [SMILES: Cc1ccccc1-c1cc2c3c(c1)N(c1ccc(C(C)(C)C)cc1-c1ccccc1)c1ccc4c(sc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1cc4c(cc1B3c1cc(C(C)(C)C)ccc1N2c1cc2c(cc1C)C(C)(C)CCC2(C)C)sc1ccc(C(C)(C)C)cc14 ; Cc1ccccc1-c1cc2c3c(c1)N(c1ccc(C(C)(C)C)cc1-c1ccccc1)c1c(ccc4c1sc1cc5c(cc14)C(C)(C)CCC5(C)C)B3c1cc(C(C)(C)C)ccc1N2c1cc2c(cc1C)C(C)(C)CCC2(C)C]

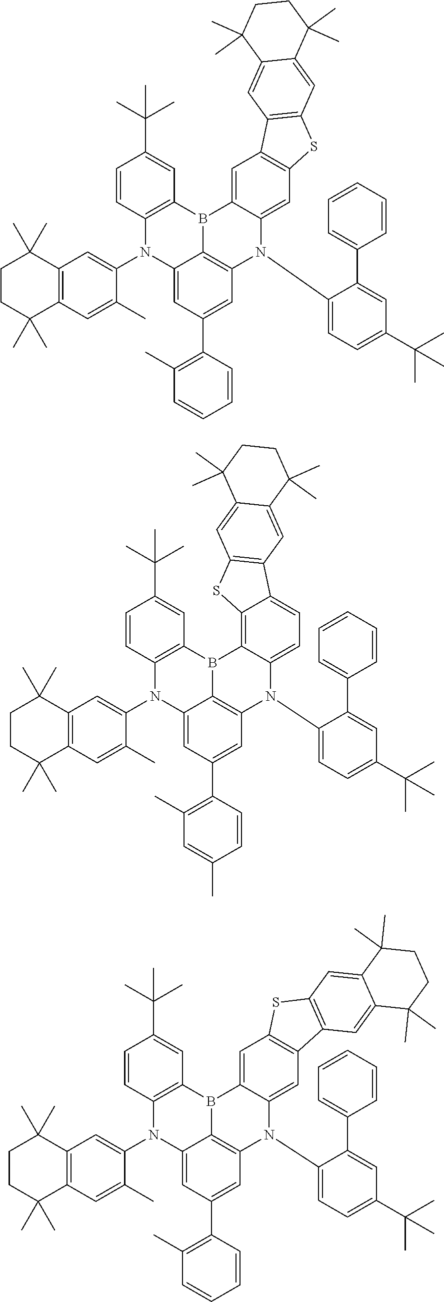

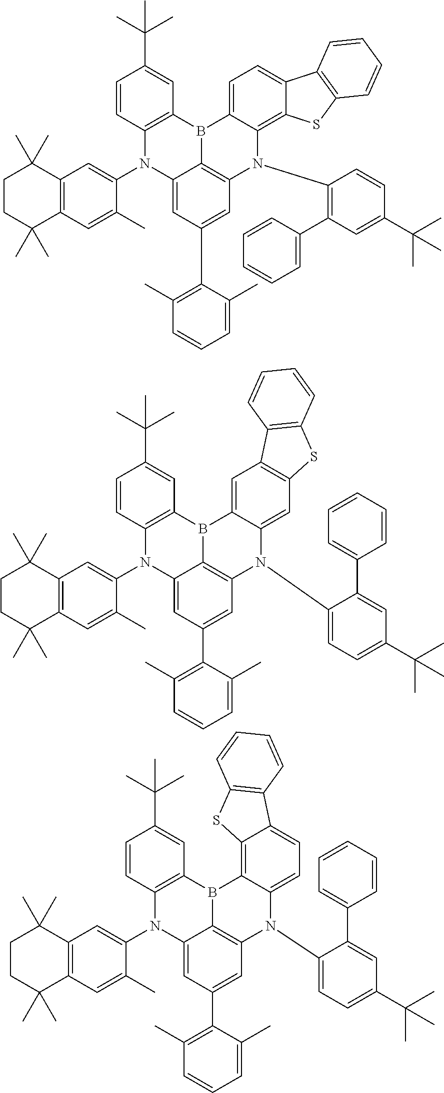

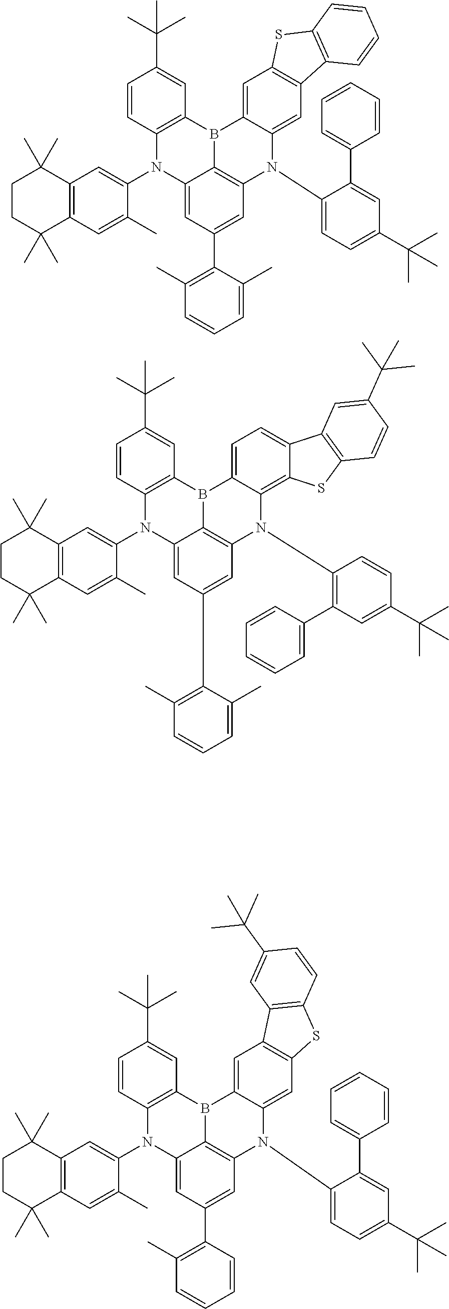 [SMILES: Cc1cc2c(cc1N1c3ccc(C(C)(C)C)cc3B3c4cc5sc6ccccc6c5cc4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(sc6ccc(C(C)(C)C)cc65)c4N(c4ccc(C(C)(C)C)cc4-c4ccccc4)c4cc(-c5c(C)cccc5C)cc1c43)C(C)(C)CCC2(C)C ; Cc1ccccc1-c1cc2c3c(c1)N(c1ccc(C(C)(C)C)cc1-c1ccccc1)c1cc4sc5ccc(C(C)(C)C)cc5c4cc1B3c1cc(C(C)(C)C)ccc1N2c1cc2c(cc1C)C(C)(C)CCC2(C)C]

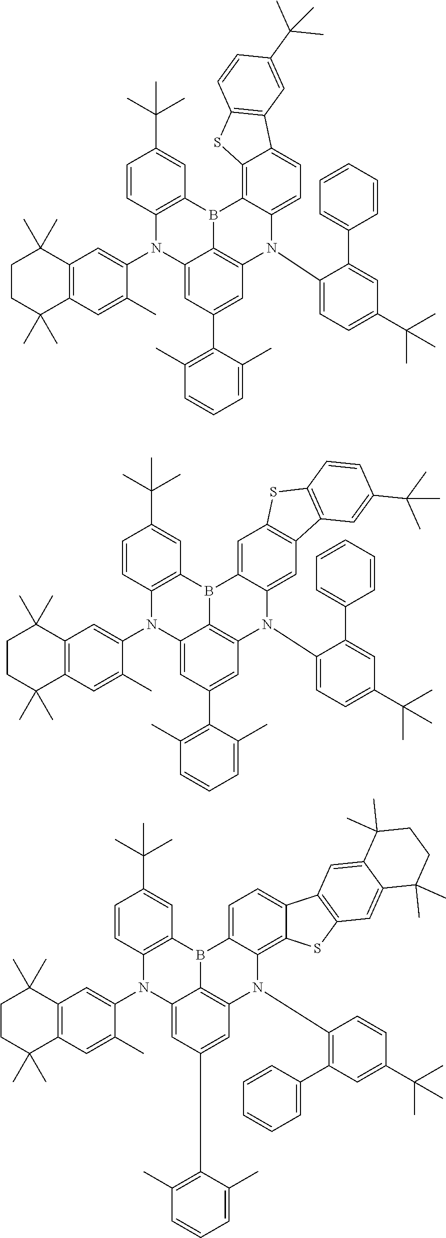 [SMILES: Cc1cc2c(cc1N1c3ccc(C(C)(C)C)cc3B3c4c1cc(-c1c(C)cccc1C)cc4N(c1ccc(C(C)(C)C)cc1-c1ccccc1)c1ccc4c(sc5ccc(C(C)(C)C)cc54)c13)C(C)(C)CCC2(C)C ; Cc1cc2c(cc1N1c3ccc(C(C)(C)C)cc3B3c4cc5sc6ccc(C(C)(C)C)cc6c5cc4N(c4ccc(C(C)(C)C)cc4-c4ccccc4)c4cc(-c5c(C)cccc5C)cc1c43)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccc(C(C)(C)C)cc4-c4ccccc4)c4cc(-c5c(C)cccc5C)cc1c43)C(C)(C)CCC2(C)C]

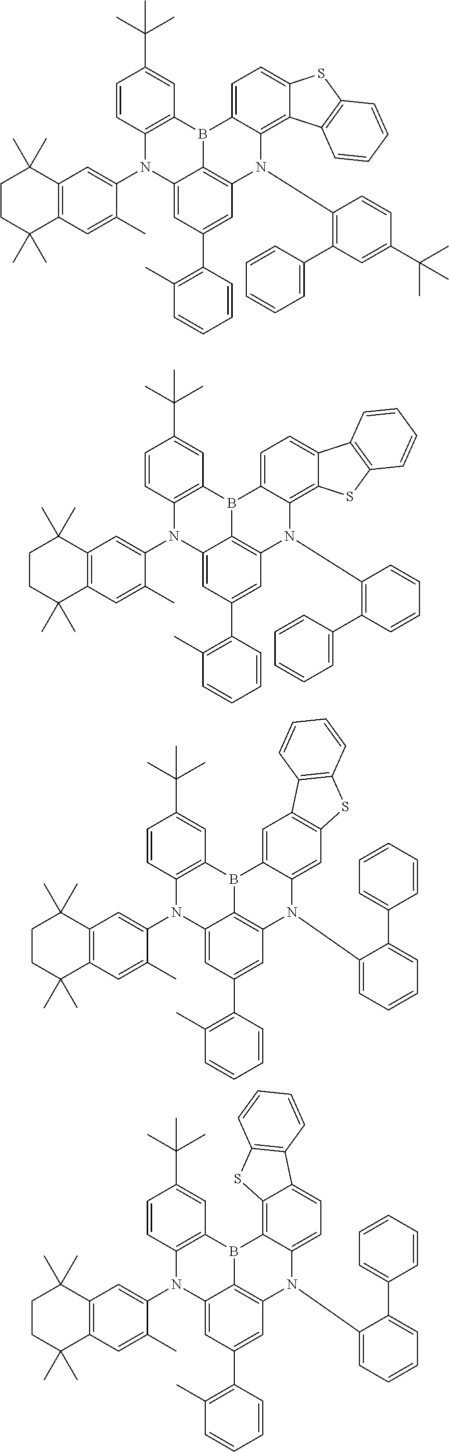

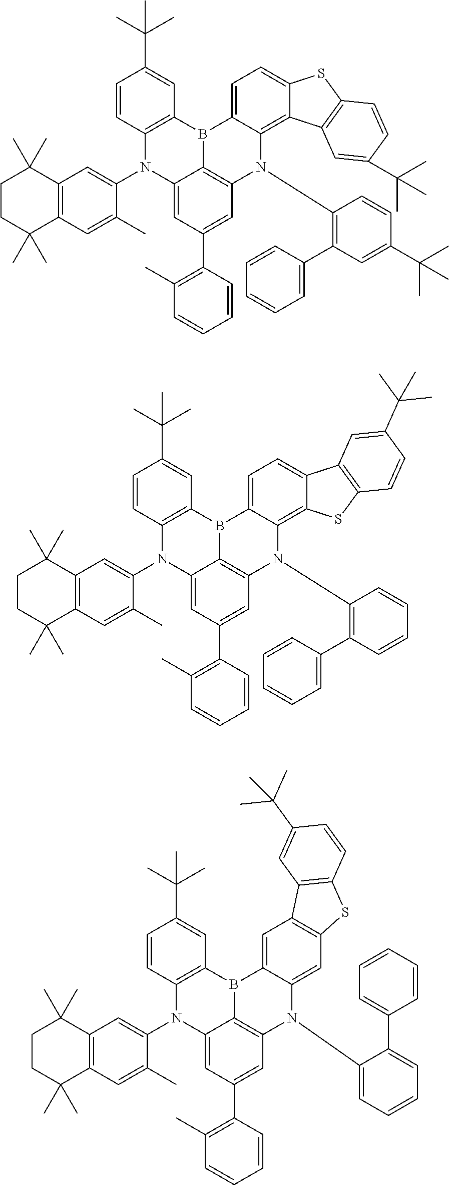 [SMILES: Cc1ccccc1-c1cc2c3c(c1)N(c1ccc(C(C)(C)C)cc1-c1ccccc1)c1c(ccc4sc5ccc(C(C)(C)C)cc5c14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1sc1ccc(C(C)(C)C)cc14)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1cc4sc5ccc(C(C)(C)C)cc5c4cc1B3c1cc(C(C)(C)C)ccc1N2c1cc2c(cc1C)C(C)(C)CCC2(C)C]

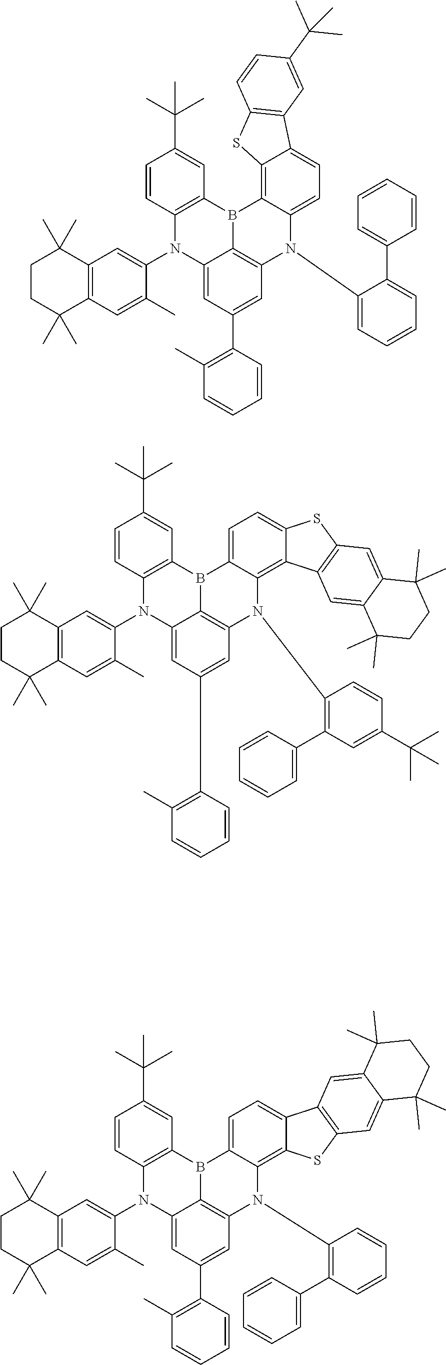 [SMILES: Cc1ccccc1-c1cc2c3c(c1)N(c1ccccc1-c1ccccc1)c1ccc4c(sc5ccc(C(C)(C)C)cc54)c1B3c1cc(C(C)(C)C)ccc1N2c1cc2c(cc1C)C(C)(C)CCC2(C)C ; Cc1ccccc1-c1cc2c3c(c1)N(c1ccc(C(C)(C)C)cc1-c1ccccc1)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1ccccc1-c1cc2c3c(c1)N(c1ccccc1-c1ccccc1)c1c(ccc4c1sc1cc5c(cc14)C(C)(C)CCC5(C)C)B3c1cc(C(C)(C)C)ccc1N2c1cc2c(cc1C)C(C)(C)CCC2(C)C]

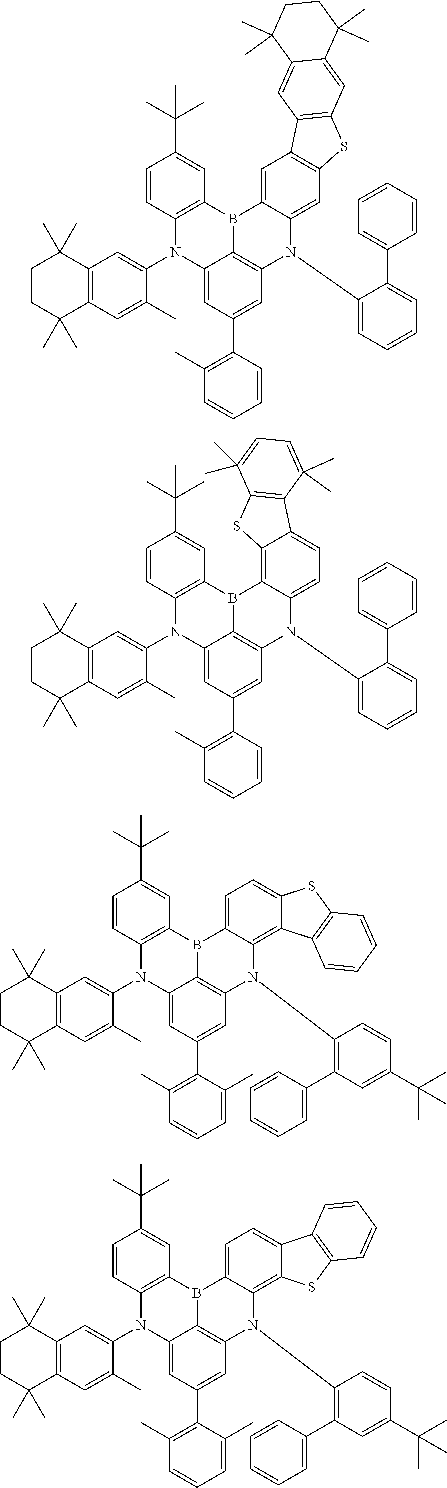

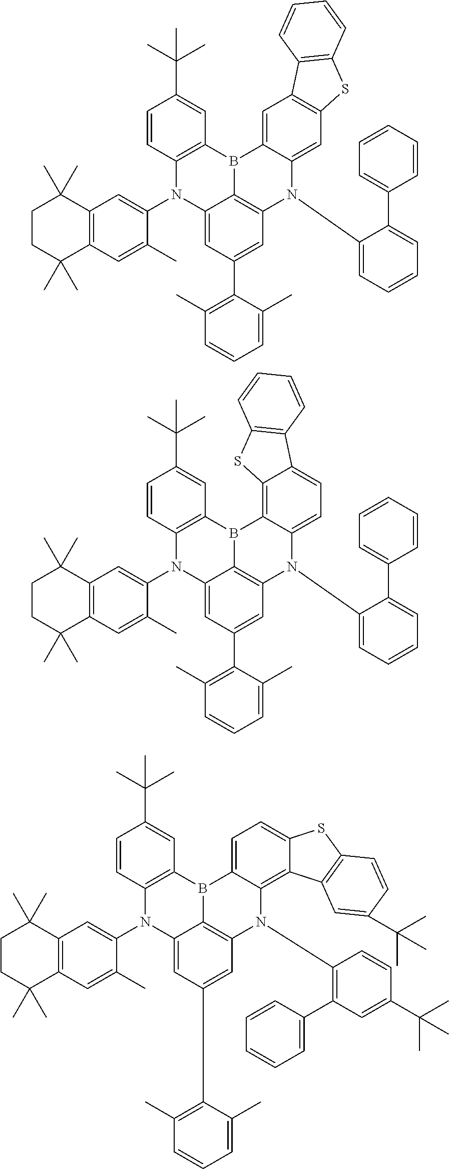

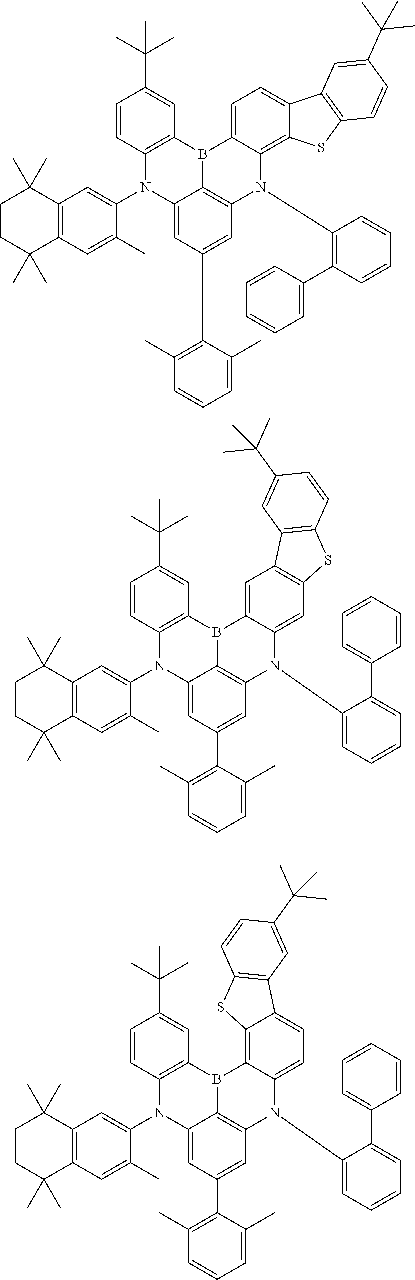

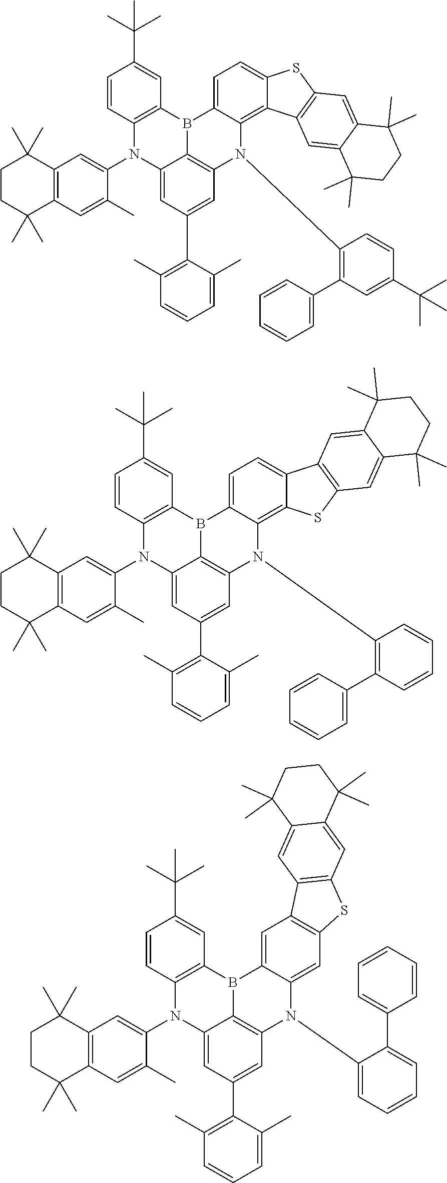

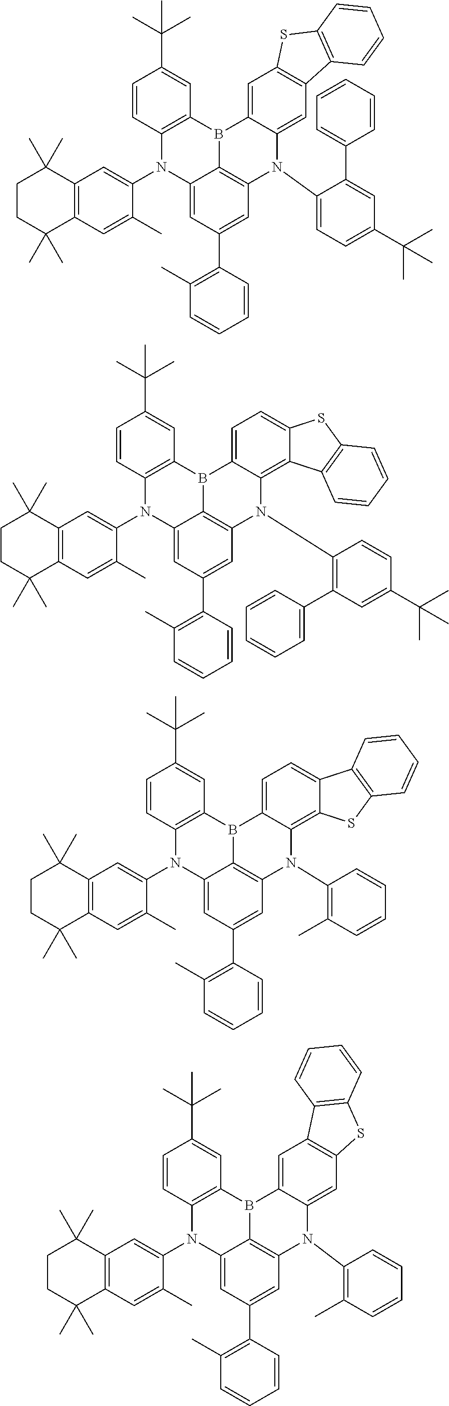

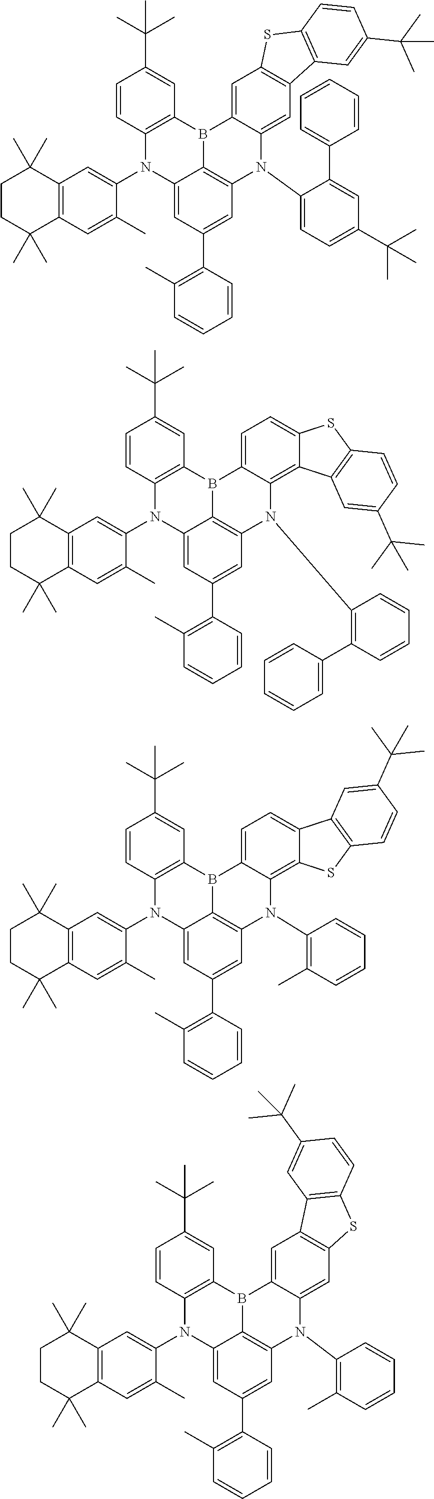

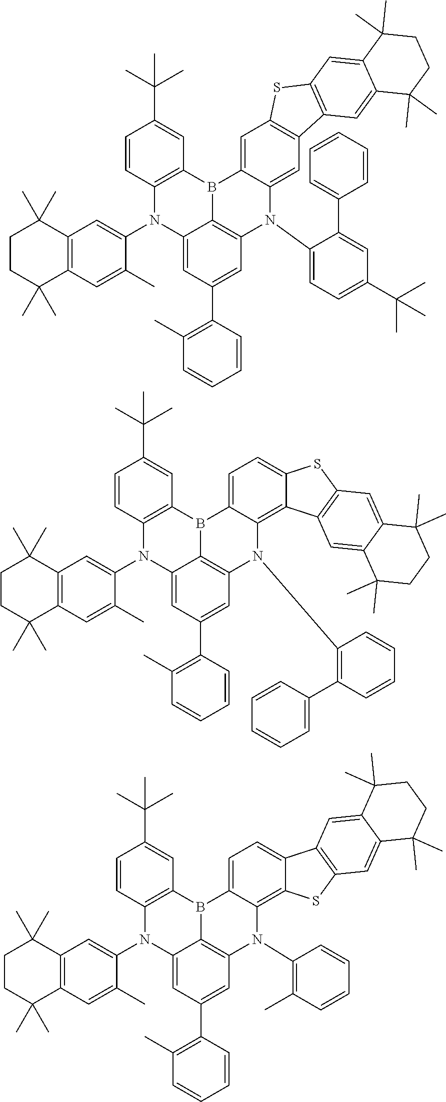

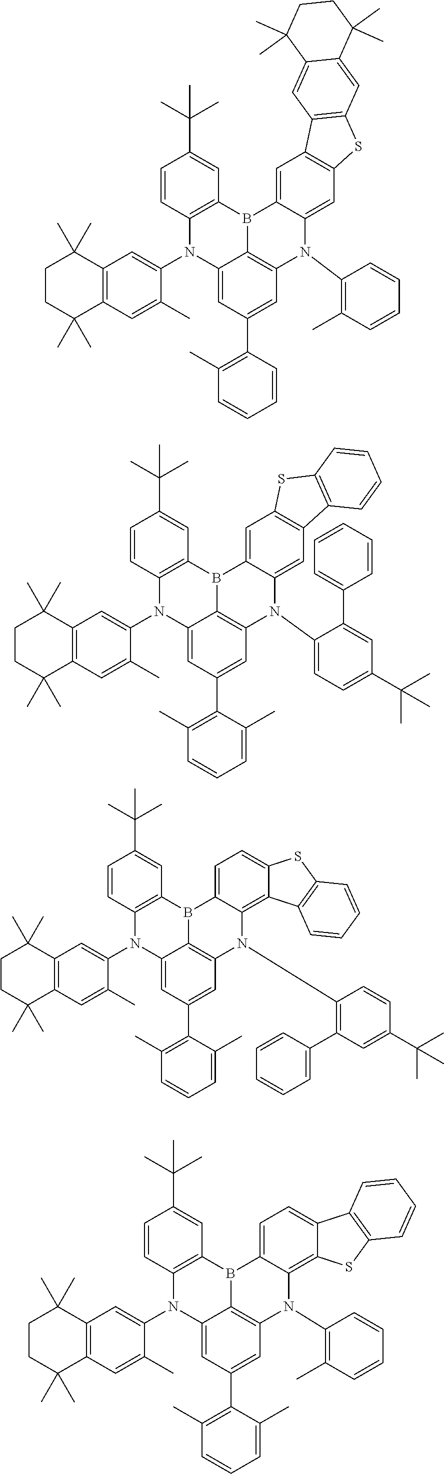

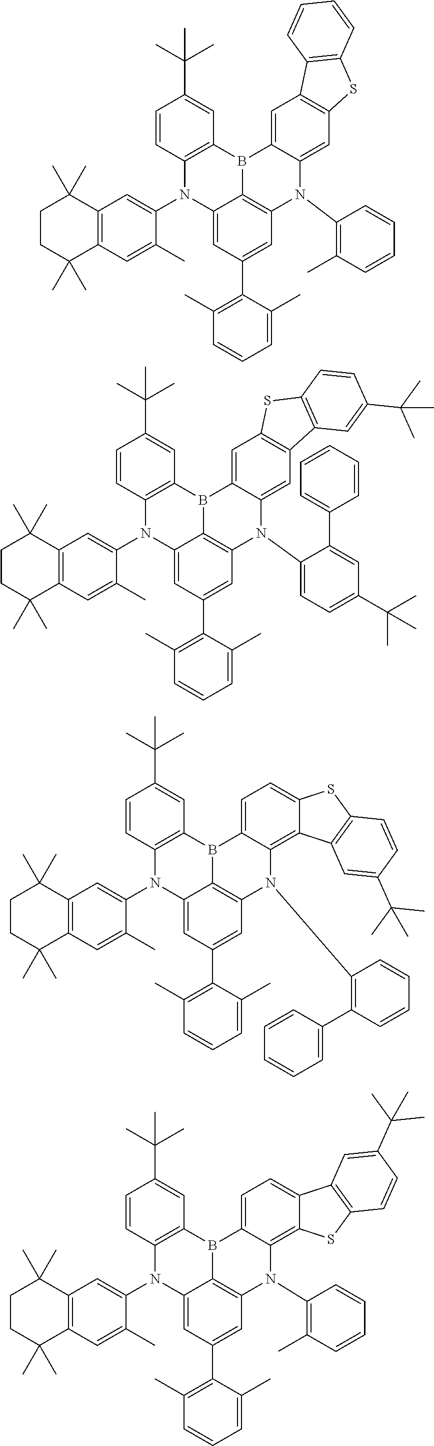

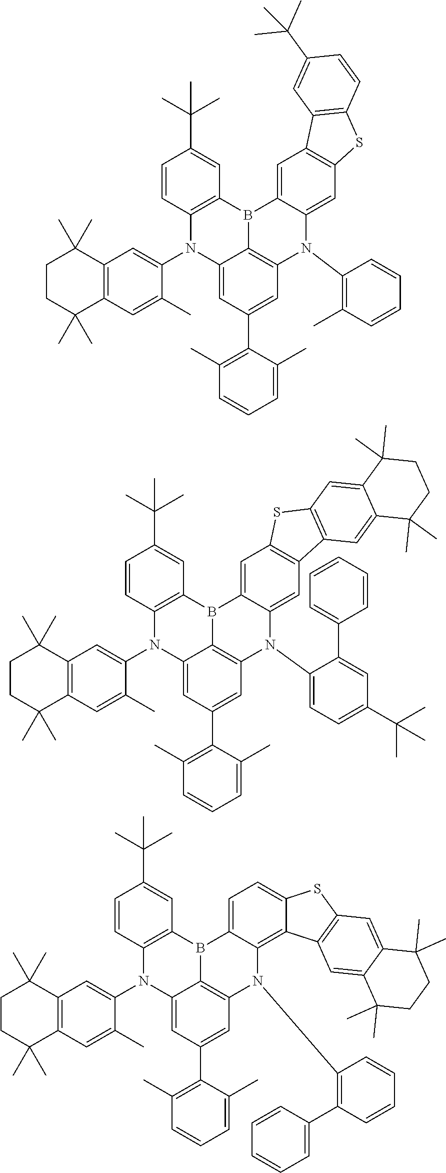

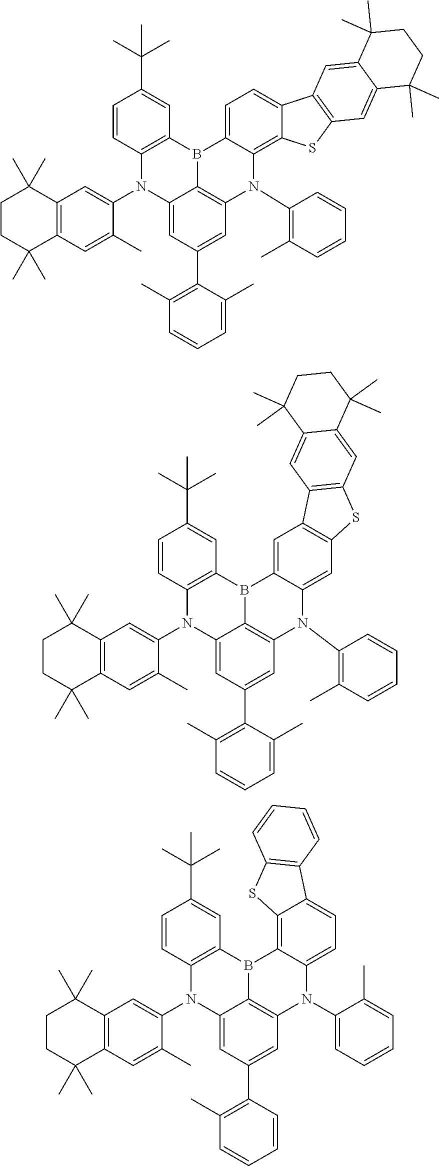

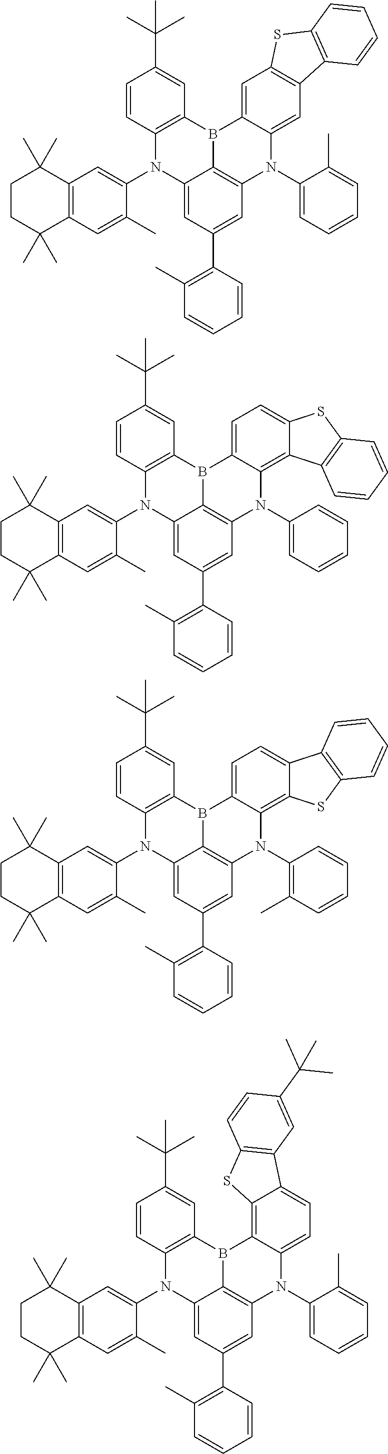

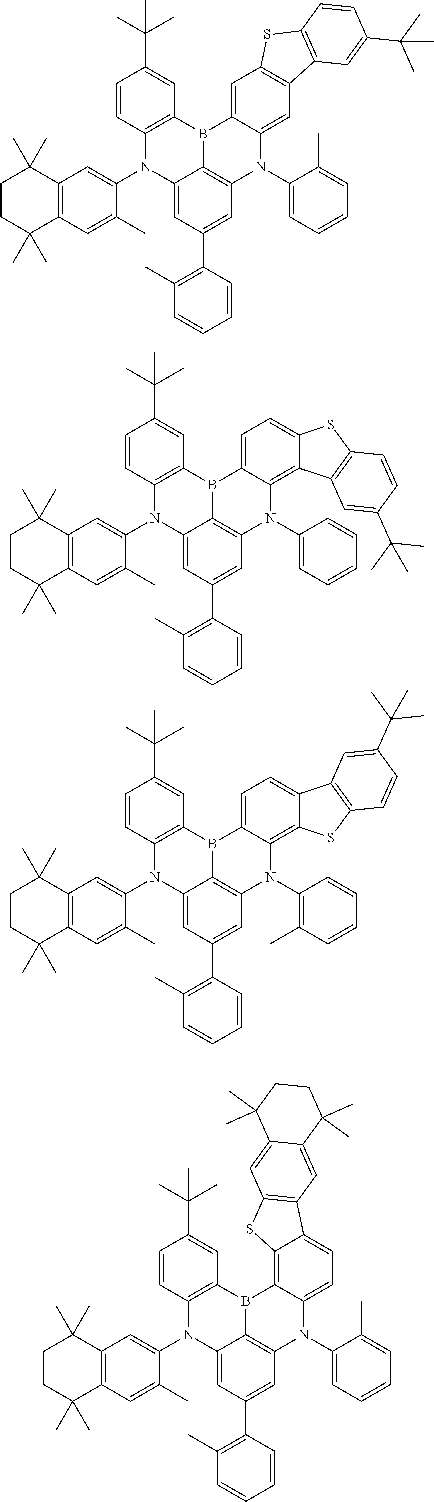

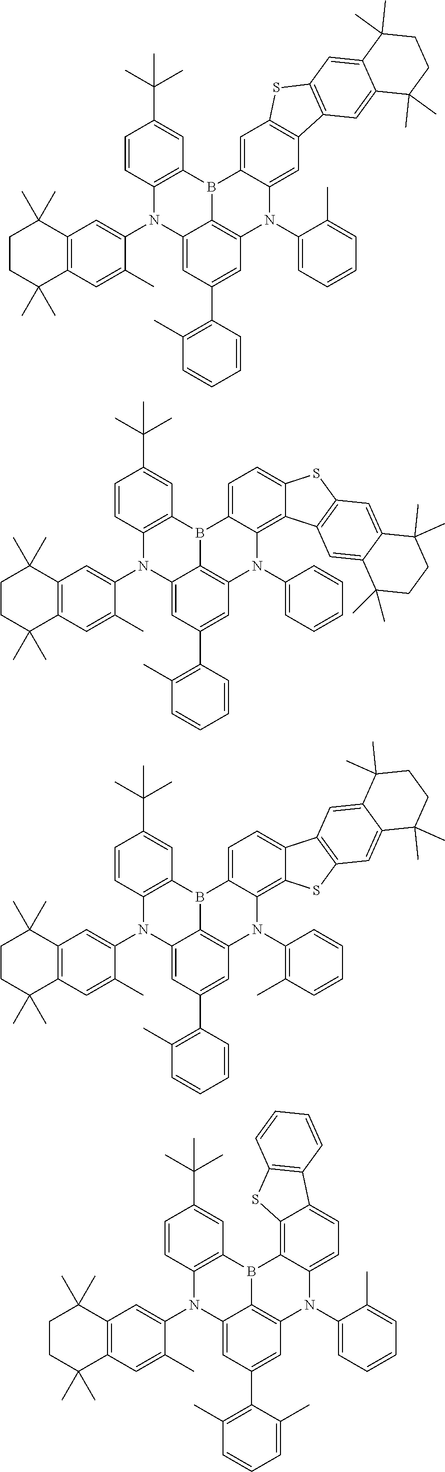

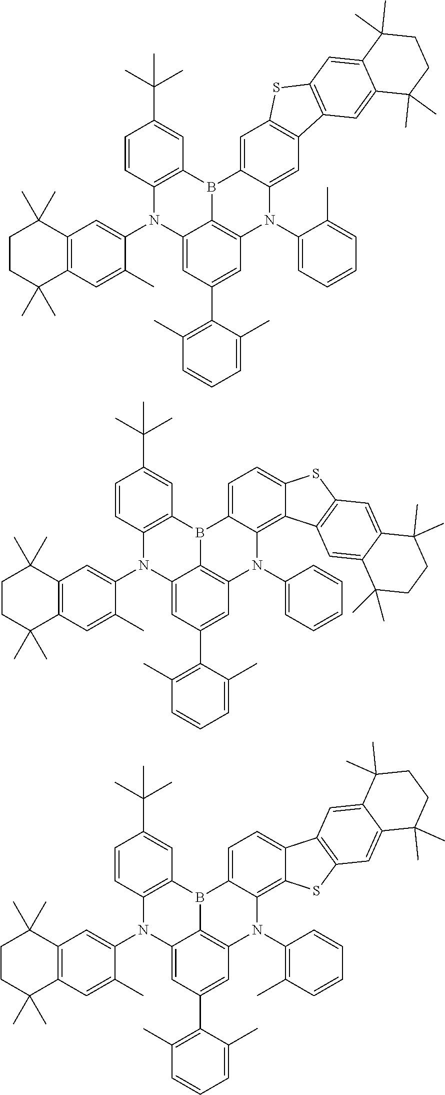 [SMILES: Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)sc1cc2c(cc13)C(C)(C)CCC2(C)C ; Cc1cc2c(cc1N1c3ccc(C(C)(C)C)cc3B3c4ccc5sc6cc7c(cc6c5c4N(c4ccccc4)c4cc(-c5c(C)cccc5C)cc1c43)C(C)(C)CCC7(C)C)C(C)(C)CCC2(C)C ; Cc1cc2c(cc1N1c3ccc(C(C)(C)C)cc3B3c4ccc5c(sc6cc7c(cc65)C(C)(C)CCC7(C)C)c4N(c4ccccc4C)c4cc(-c5c(C)cccc5C)cc1c43)C(C)(C)CCC2(C)C]

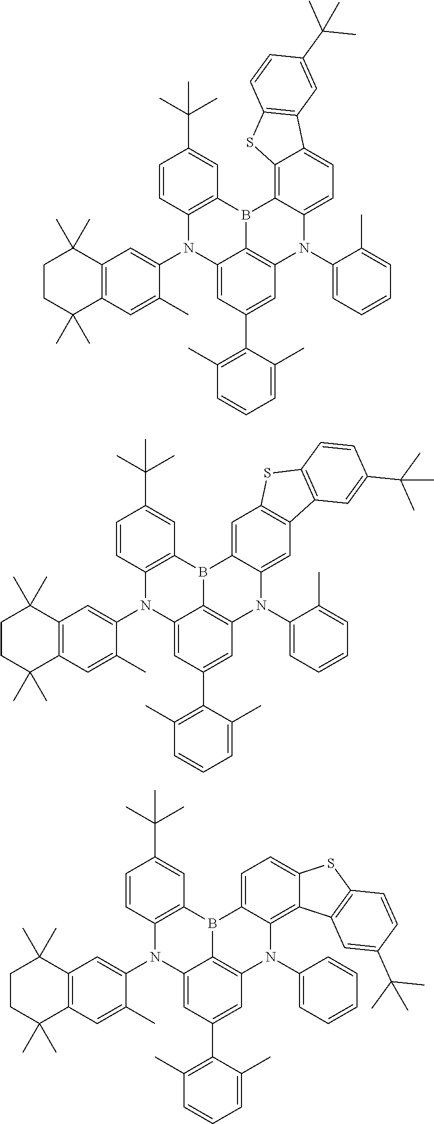

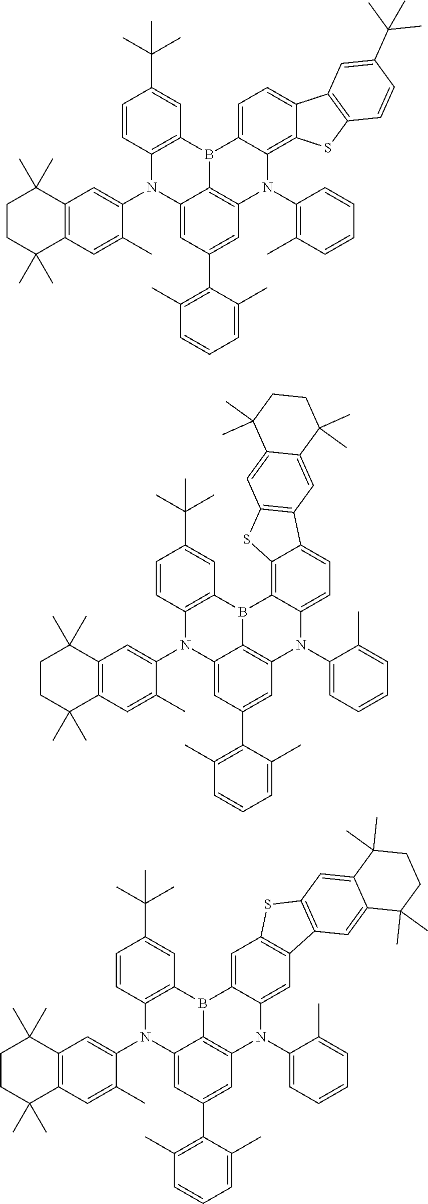 [SMILES: Cc1cc2c(cc1N1c3ccc(C(C)(C)C)cc3B3c4ccc5c(sc6ccc(C(C)(C)C)cc65)c4N(c4ccccc4C)c4cc(-c5c(C)cccc5C)cc1c43)C(C)(C)CCC2(C)C ; Cc1cc2c(cc1N1c3ccc(C(C)(C)C)cc3B3c4c1cc(-c1c(C)cccc1C)cc4N(c1ccccc1C)c1ccc4c(sc5cc6c(cc54)C(C)(C)CCC6(C)C)c13)C(C)(C)CCC2(C)C ; Cc1ccccc1N1c2cc3c(cc2B2c4cc(C(C)(C)C)ccc4N(c4cc5c(cc4C)C(C)(C)CCC5(C)C)c4cc(-c5c(C)cccc5C)cc1c42)sc1cc2c(cc13)C(C)(C)CCC2(C)C]

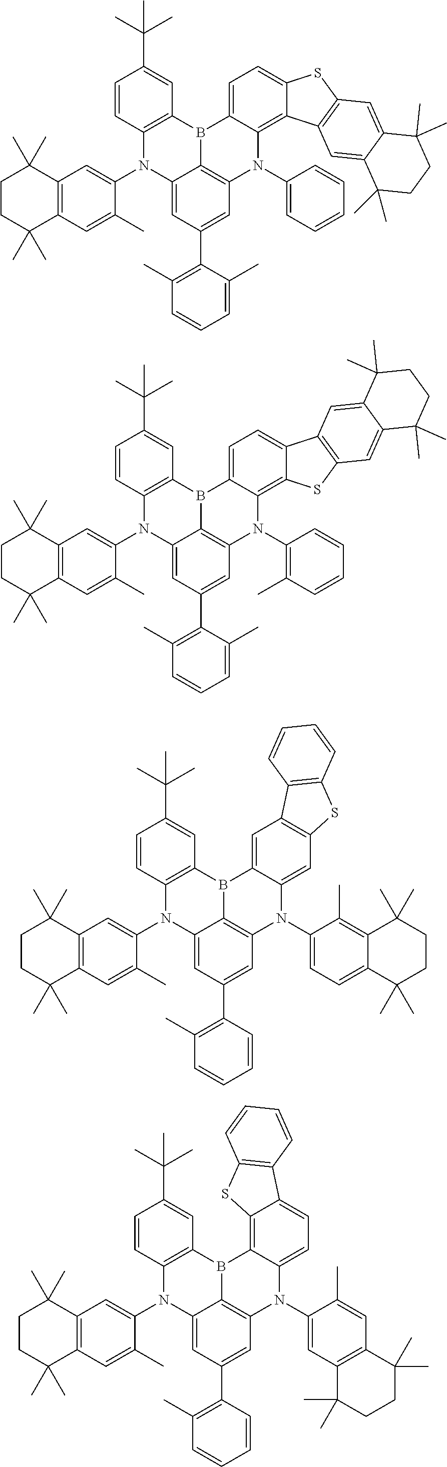

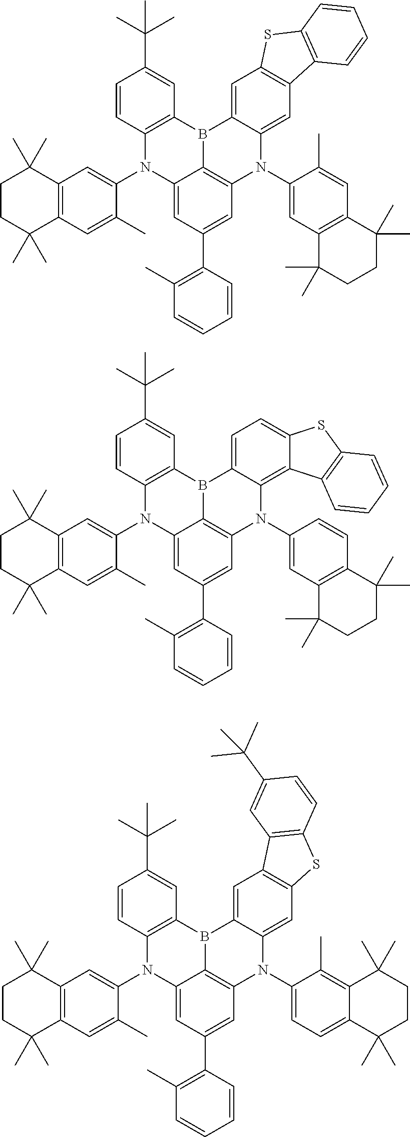

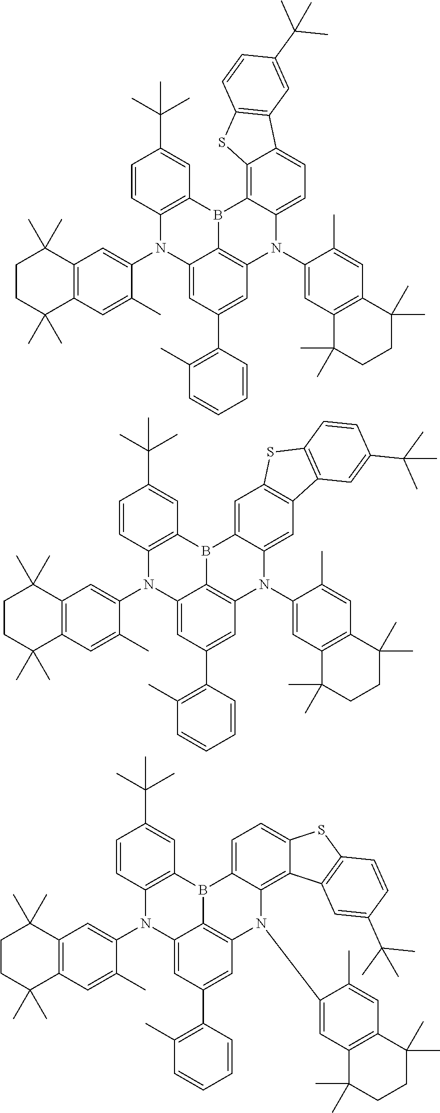

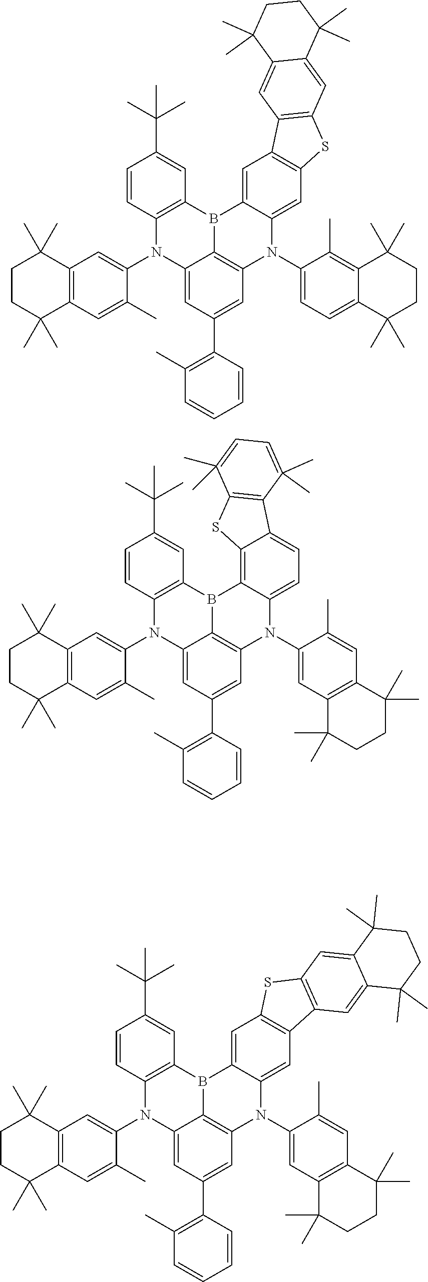

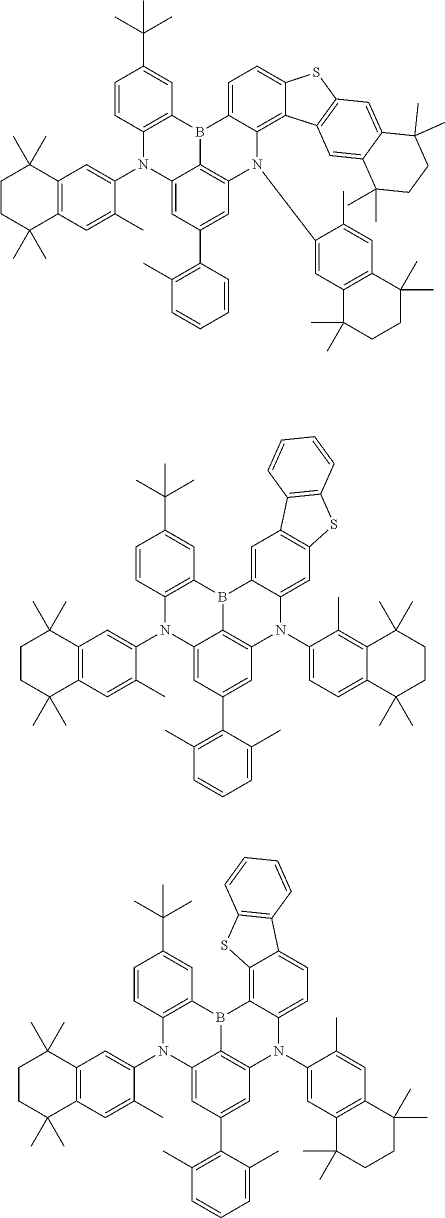 [SMILES: Cc1ccccc1-c1cc2c3c(c1)N(c1cc4c(cc1C)C(C)(C)CCC4(C)C)c1c(ccc4sc5cc6c(cc5c14)C(C)(C)CCC6(C)C)B3c1cc(C(C)(C)C)ccc1N2c1cc2c(cc1C)C(C)(C)CCC2(C)C ; Cc1cc2c(cc1N1c3ccc(C(C)(C)C)cc3B3c4cc5c(cc4N(c4ccc6c(c4C)C(C)(C)CCC6(C)C)c4cc(-c6c(C)cccc6C)cc1c43)sc1ccccc15)C(C)(C)CCC2(C)C ; Cc1cc2c(cc1N1c3ccc(C(C)(C)C)cc3B3c4c1cc(-c1c(C)cccc1C)cc4N(c1cc4c(cc1C)C(C)(C)CCC4(C)C)c1ccc4c(sc5ccccc54)c13)C(C)(C)CCC2(C)C]

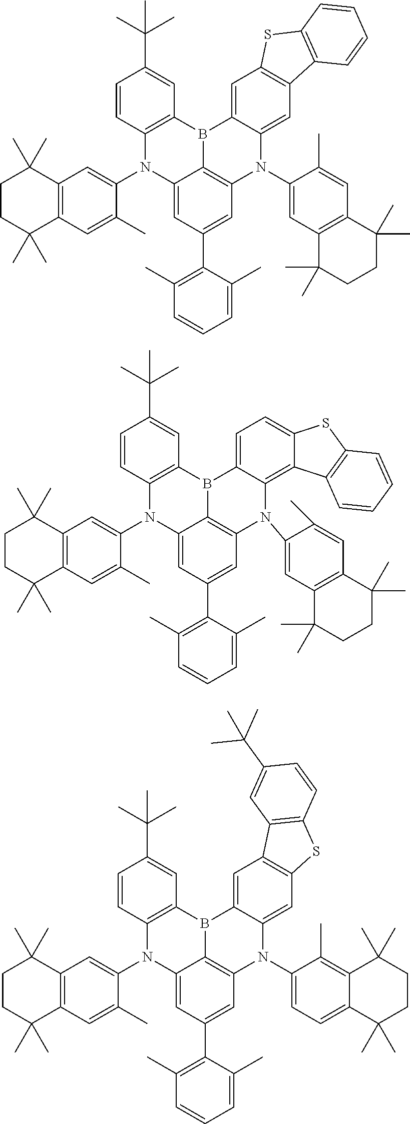

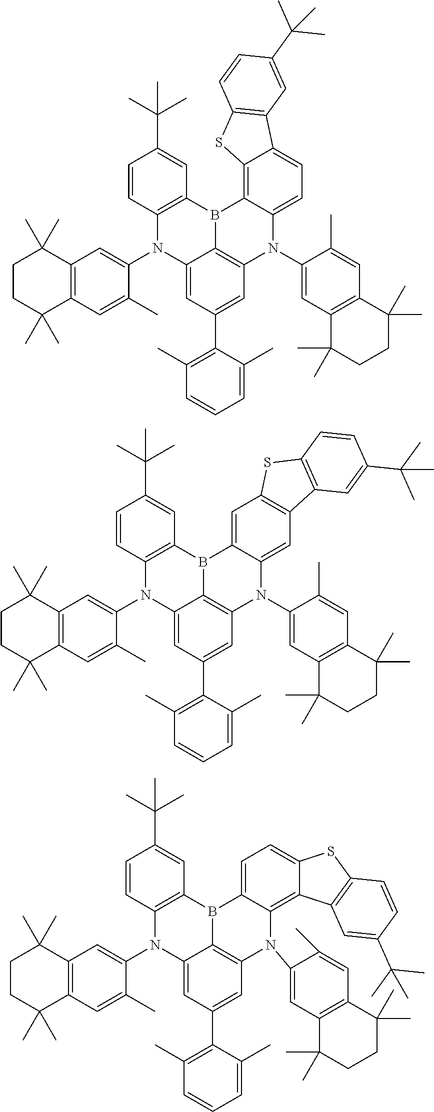

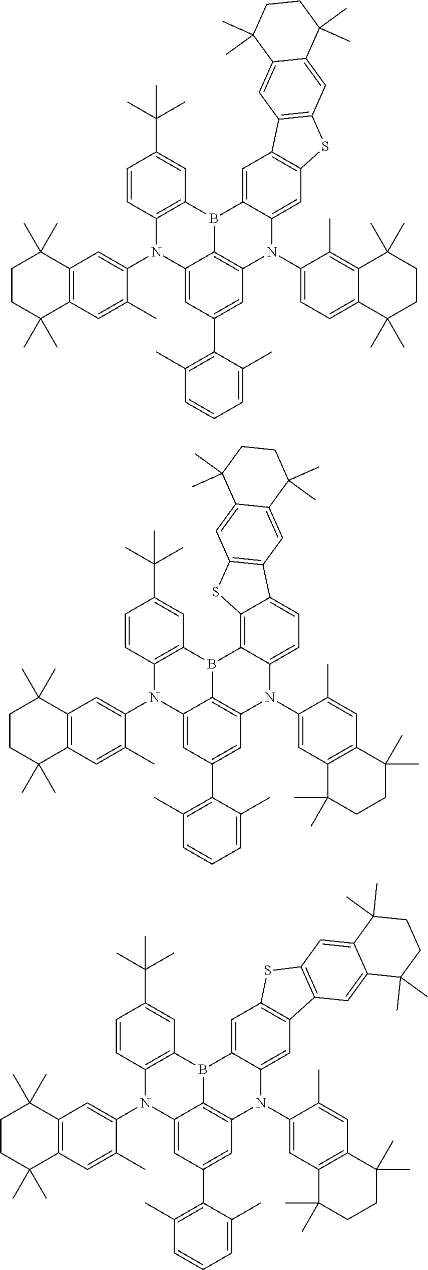

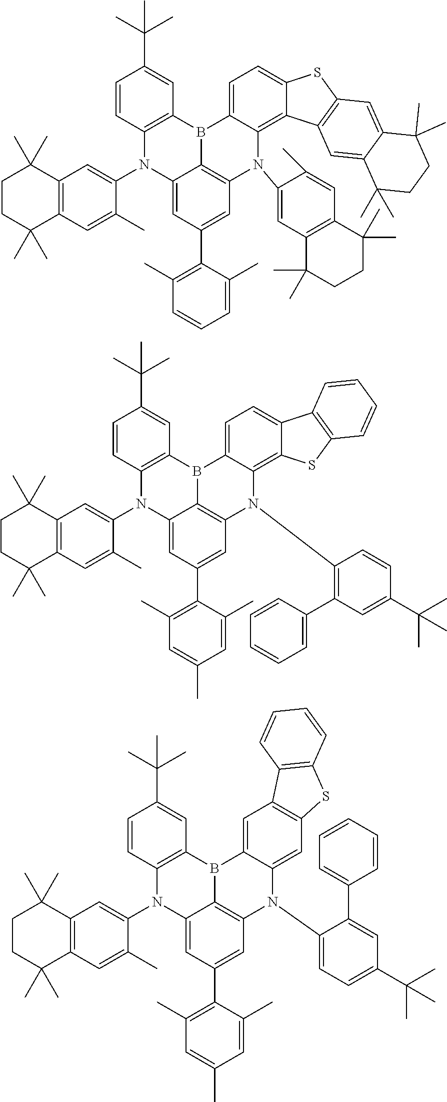

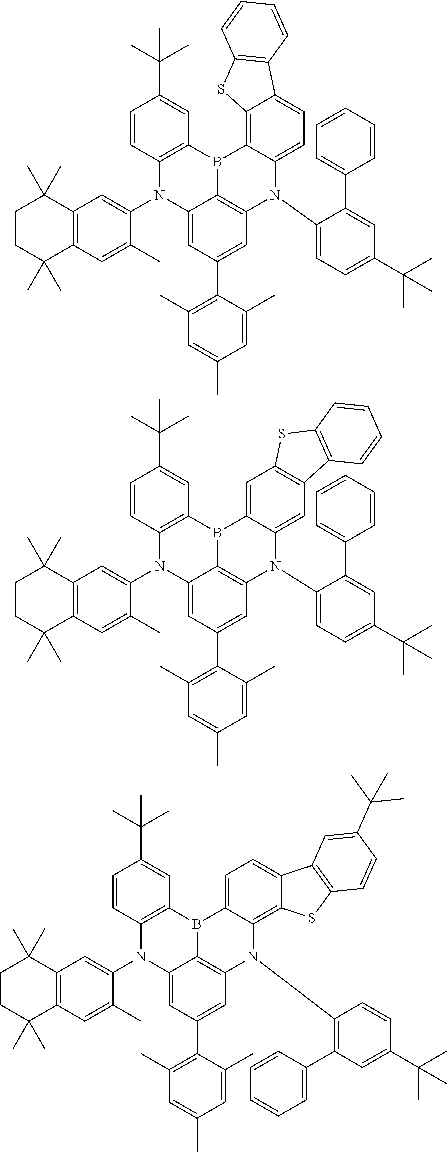

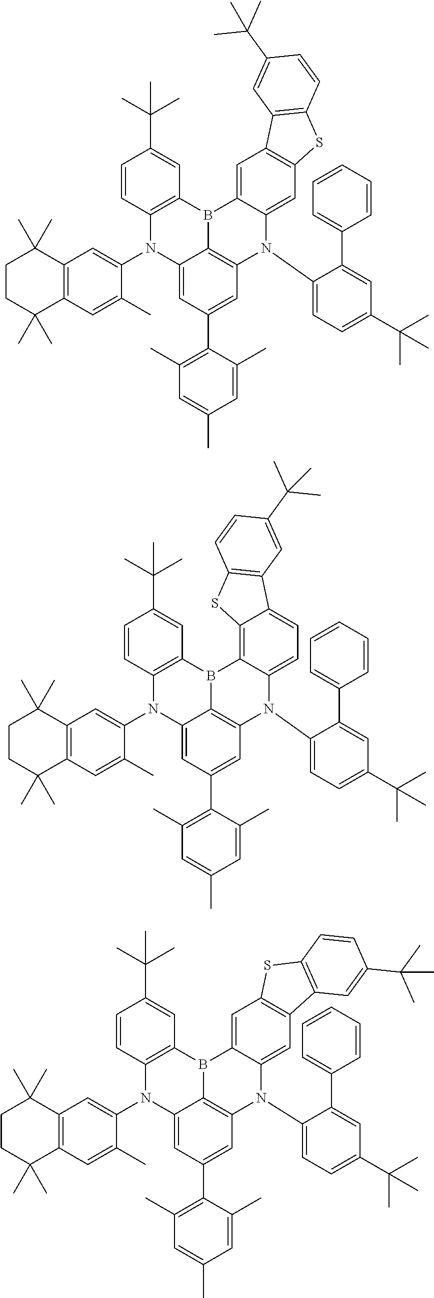 [SMILES: Cc1cc(C)c(-c2cc3c4c(c2)N(c2ccc(C(C)(C)C)cc2-c2ccccc2)c2cc5sc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2ccc5c(sc6ccc(C(C)(C)C)cc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)sc2ccc(C(C)(C)C)cc25)c(C)c1]

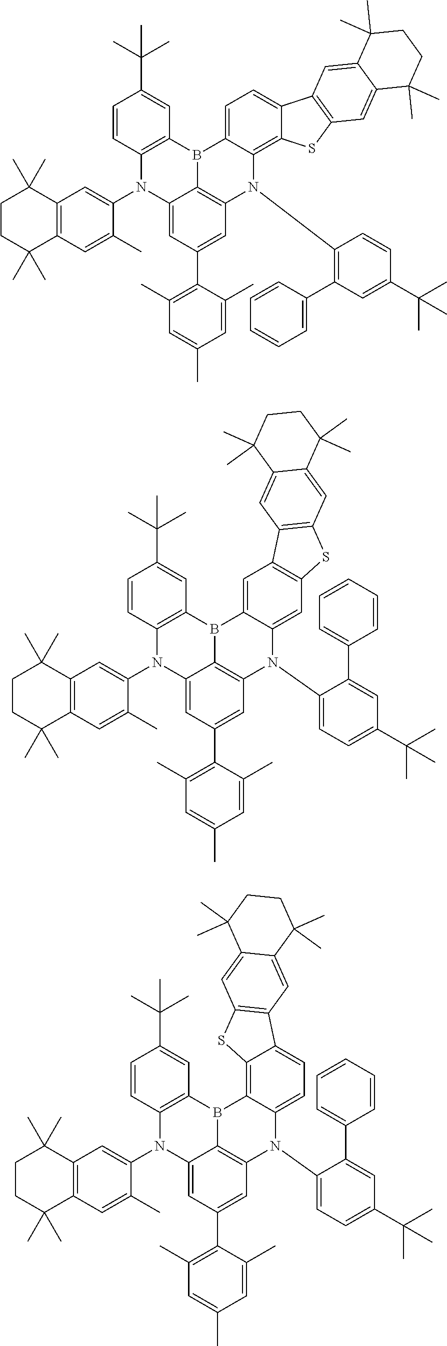

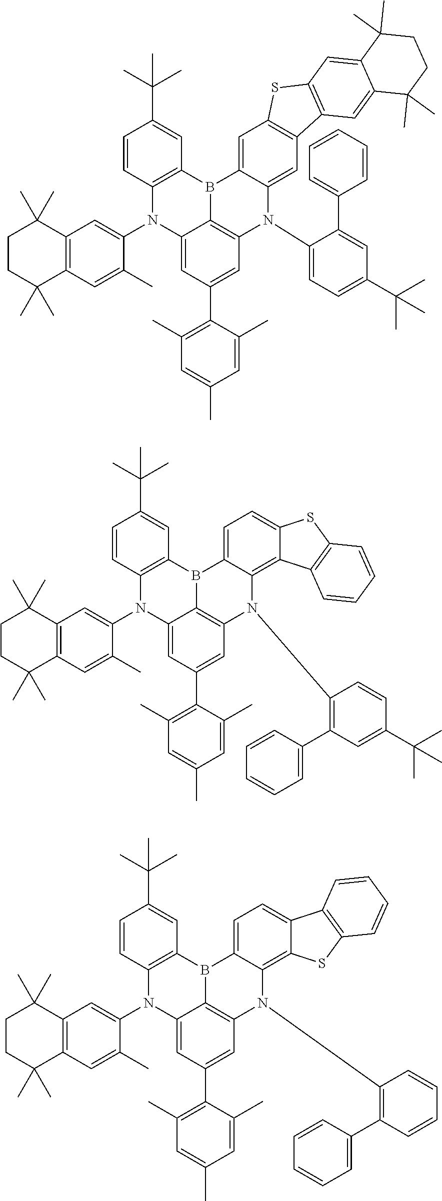 [SMILES: Cc1cc(C)c(-c2cc3c4c(c2)N(c2ccc(C(C)(C)C)cc2-c2ccccc2)c2cc5c(cc2B4c2cc(C(C)(C)C)ccc2N3c2cc3c(cc2C)C(C)(C)CCC3(C)C)sc2cc3c(cc25)C(C)(C)CCC3(C)C)c(C)c1 ; Cc1cc(C)c(-c2cc3c4c(c2)N(c2ccc(C(C)(C)C)cc2-c2ccccc2)c2c(ccc5sc6ccccc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2sc2ccccc25)B4c2cc(C(C)(C)C)ccc2N3c2cc3c(cc2C)C(C)(C)CCC3(C)C)c(C)c1]

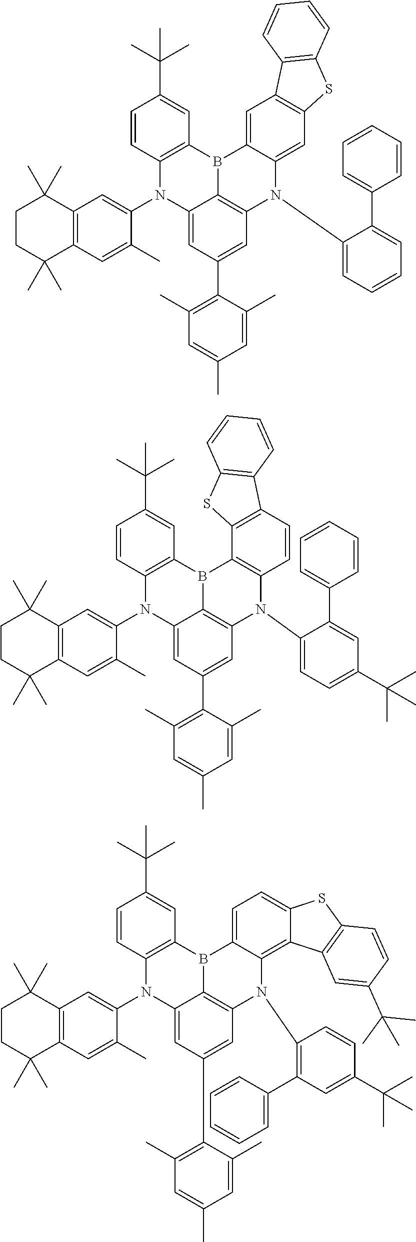

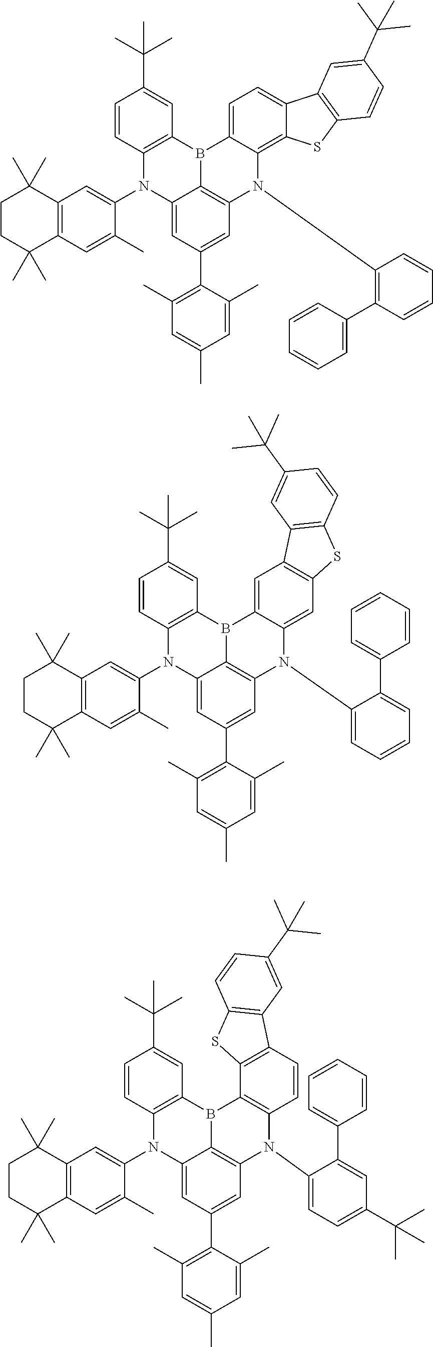 [SMILES: Cc1cc(C)c(-c2cc3c4c(c2)N(c2ccccc2-c2ccccc2)c2c(ccc5c2sc2ccc(C(C)(C)C)cc25)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5sc6ccc(C(C)(C)C)cc6c5cc2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccc(C(C)(C)C)cc2-c2ccccc2)c2ccc5c(sc6ccc(C(C)(C)C)cc65)c2B4c2cc(C(C)(C)C)ccc2N3c2cc3c(cc2C)C(C)(C)CCC3(C)C)c(C)c1]

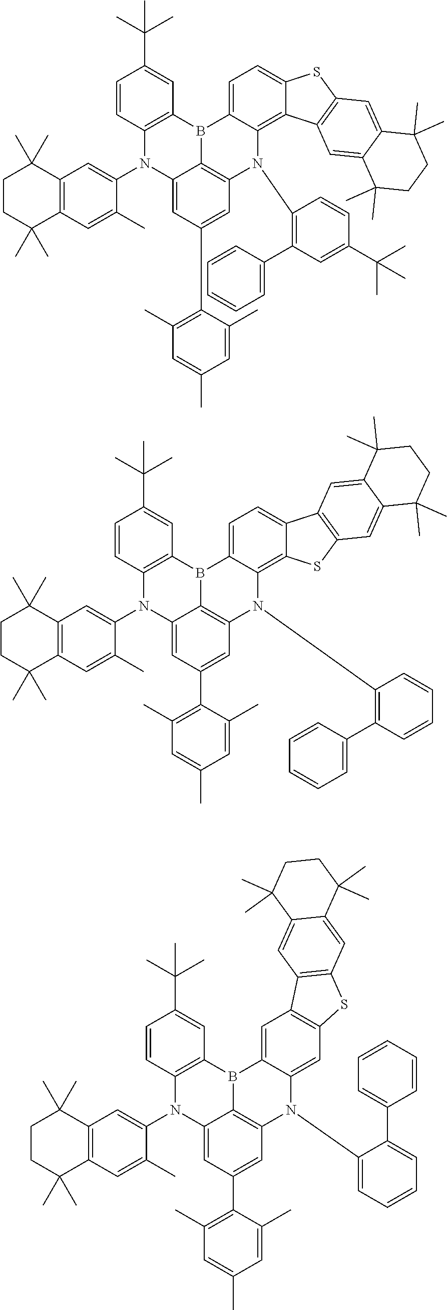 [SMILES: Cc1cc(C)c(-c2cc3c4c(c2)N(c2ccc(C(C)(C)C)cc2-c2ccccc2)c2c(ccc5sc6cc7c(cc6c25)C(C)(C)CCC7(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2c(ccc5c2sc2cc6c(cc25)C(C)(C)CCC6(C)C)B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2-c2ccccc2)c2cc5sc6cc7c(cc6c5cc2B4c2cc(C(C)(C)C)ccc2N3c2cc3c(cc2C)C(C)(C)CCC3(C)C)C(C)(C)CCC7(C)C)c(C)c1]

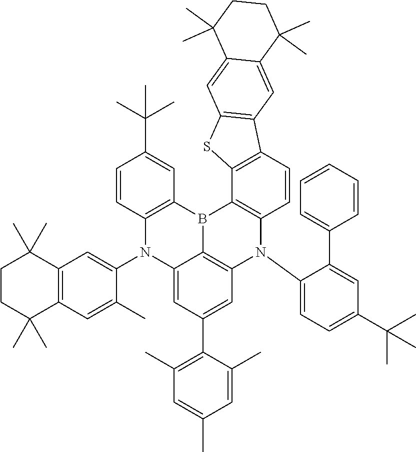 [SMILES: Cc1cc(C)c(-c2cc3c4c(c2)N(c2ccc(C(C)(C)C)cc2-c2ccccc2)c2ccc5c(sc6cc7c(cc65)C(C)(C)CCC7(C)C)c2B4c2cc(C(C)(C)C)ccc2N3c2cc3c(cc2C)C(C)(C)CCC3(C)C)c(C)c1]

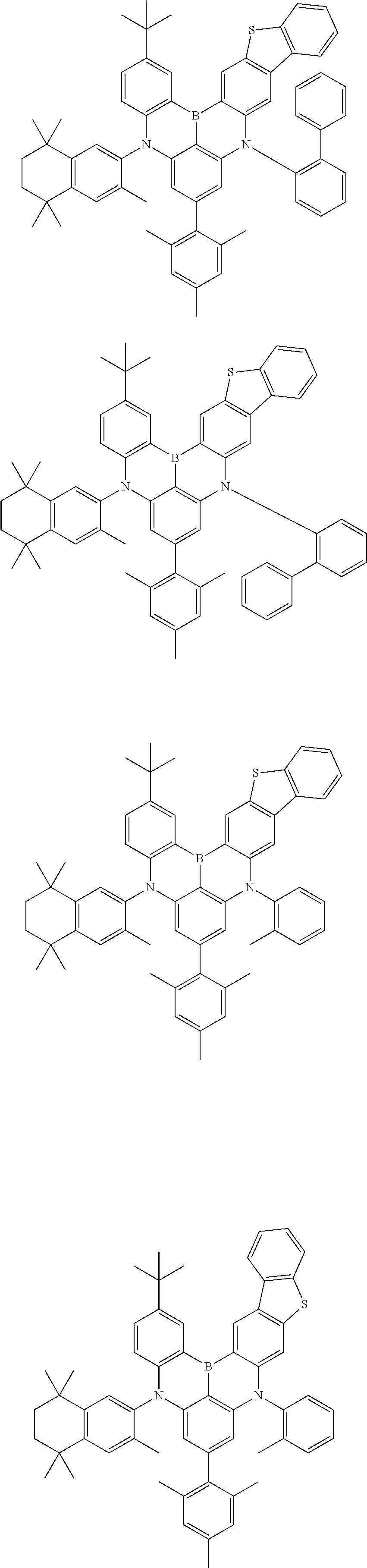 [SMILES: Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)sc2ccccc25)c(C)c1 ; Cc1cc(C)c(-c2cc3c4c(c2)N(c2ccccc2-c2ccccc2)c2cc5c(cc2B4c2cc(C(C)(C)C)ccc2N3c2cc3c(cc2C)C(C)(C)CCC3(C)C)sc2ccccc25)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)sc2ccccc25)c(C)c1 ; Cc1cc(C)c(-c2cc3c4c(c2)N(c2ccccc2C)c2cc5sc6ccccc6c5cc2B4c2cc(C(C)(C)C)ccc2N3c2cc3c(cc2C)C(C)(C)CCC3(C)C)c(C)c1]

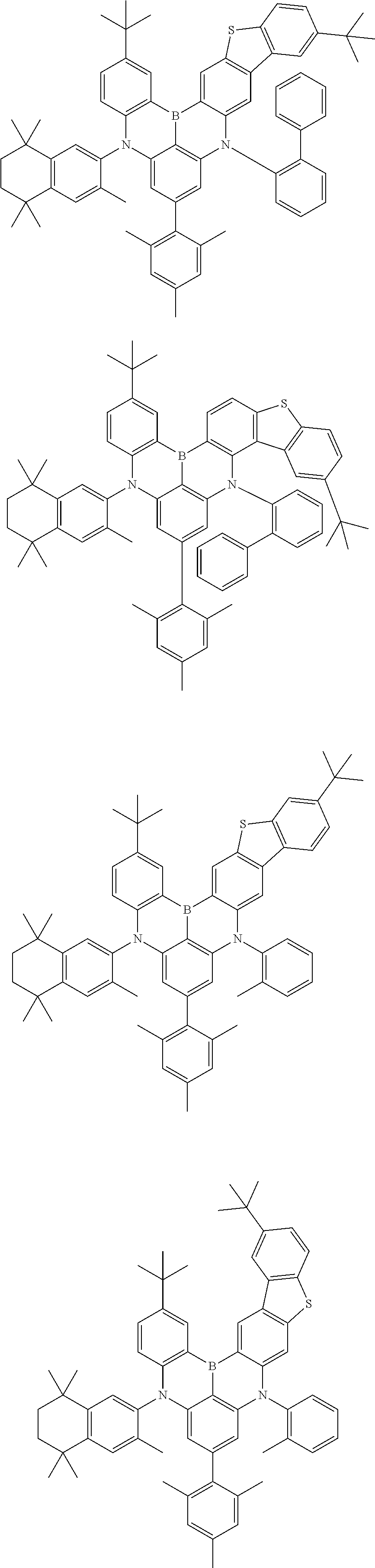

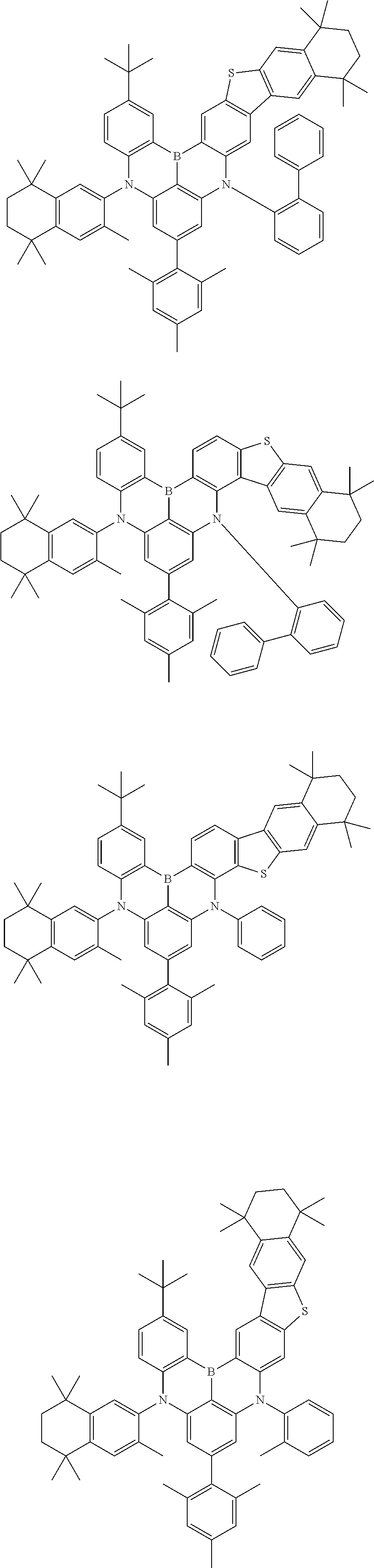

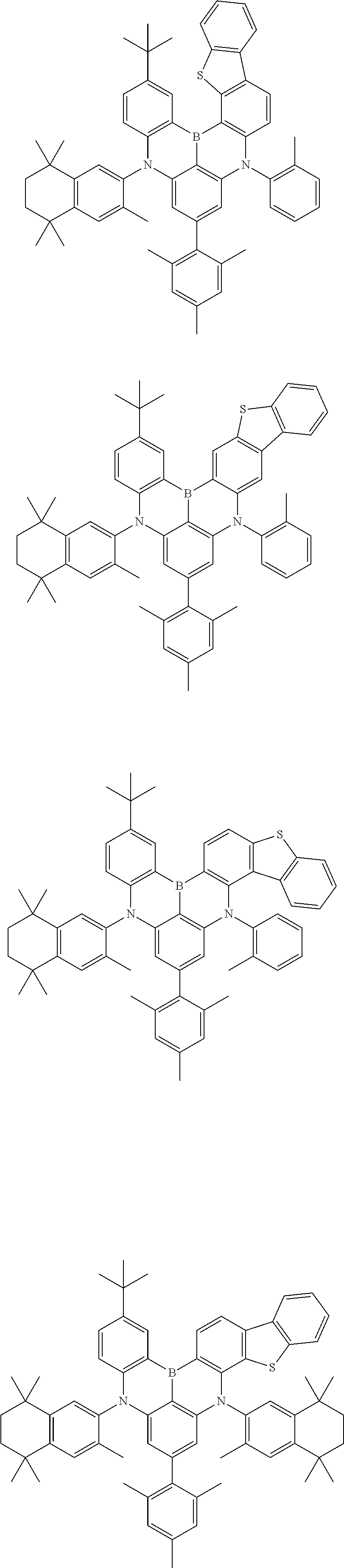 [SMILES: Cc1cc(C)c(-c2cc3c4c(c2)N(c2ccccc2C)c2ccc5c(sc6ccccc65)c2B4c2cc(C(C)(C)C)ccc2N3c2cc3c(cc2C)C(C)(C)CCC3(C)C)c(C)c1 ; Cc1cc(C)c(-c2cc3c4c(c2)N(c2ccccc2C)c2cc5c(cc2B4c2cc(C(C)(C)C)ccc2N3c2cc3c(cc2C)C(C)(C)CCC3(C)C)sc2ccccc25)c(C)c1 ; Cc1cc(C)c(-c2cc3c4c(c2)N(c2ccccc2C)c2c(ccc5sc6ccccc6c25)B4c2cc(C(C)(C)C)ccc2N3c2cc3c(cc2C)C(C)(C)CCC3(C)C)c(C)c1 ; Cc1cc(C)c(-c2cc3c4c(c2)N(c2cc5c(cc2C)C(C)(C)CCC5(C)C)c2c(ccc5c2sc2ccccc25)B4c2cc(C(C)(C)C)ccc2N3c2cc3c(cc2C)C(C)(C)CCC3(C)C)c(C)c1]

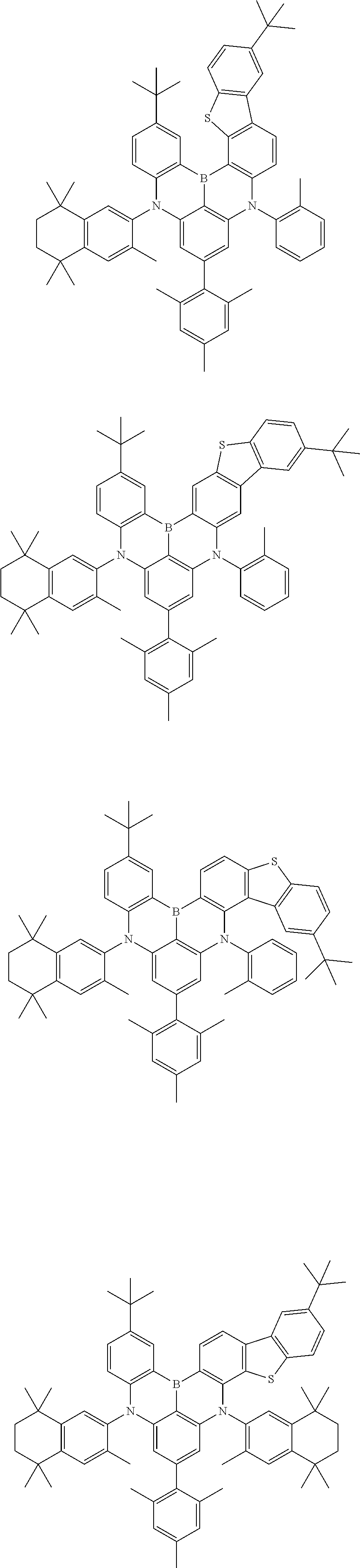

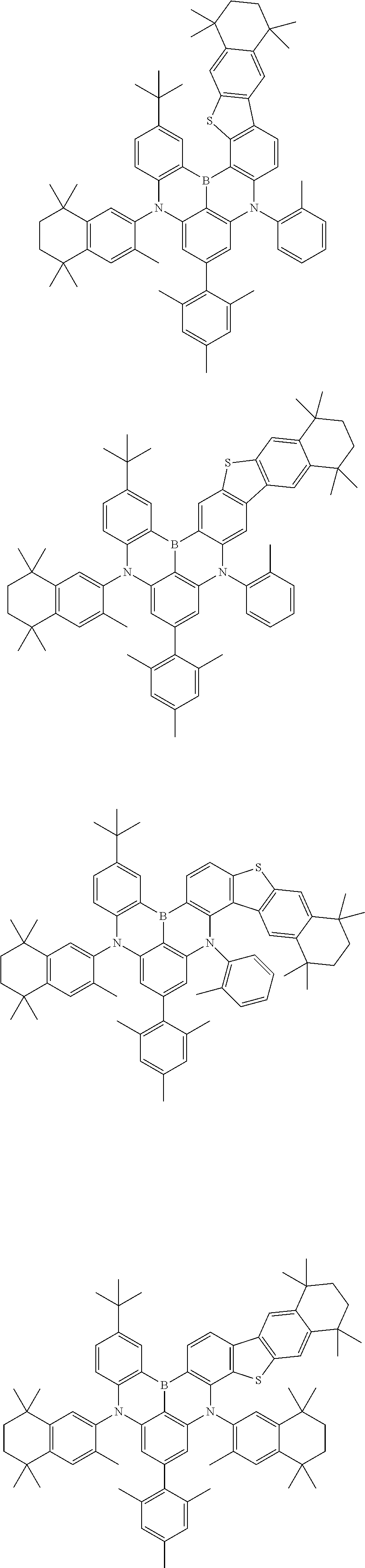

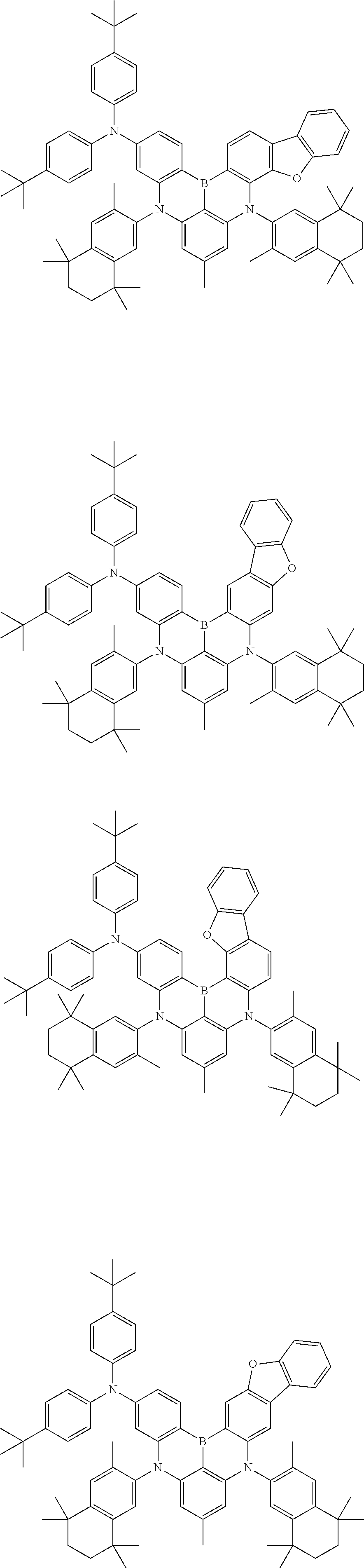

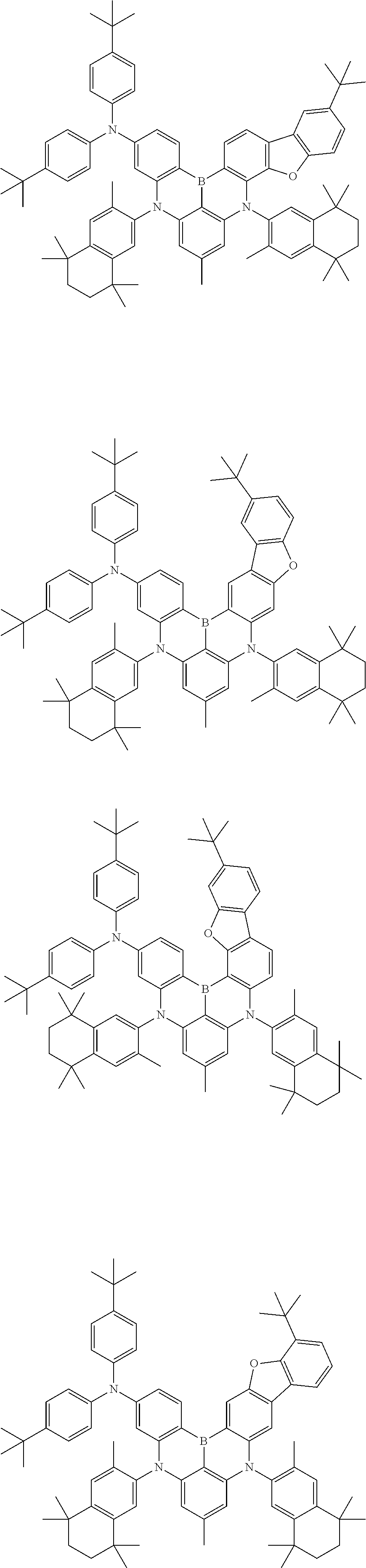

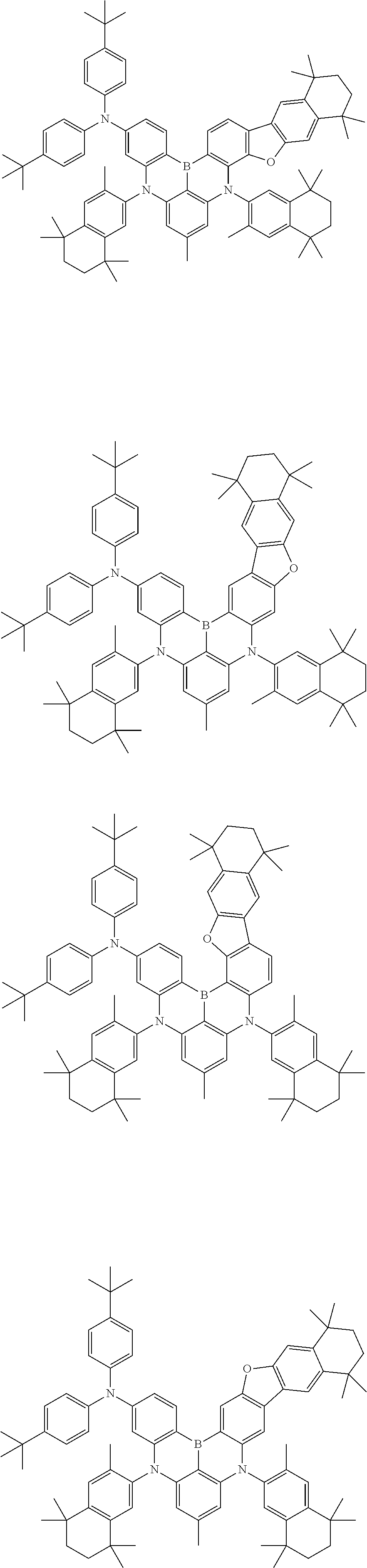

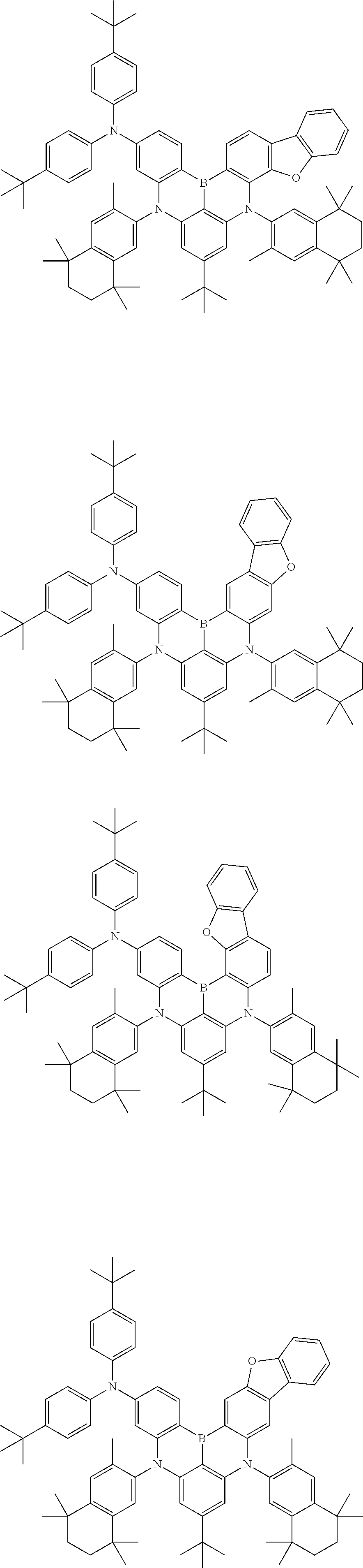

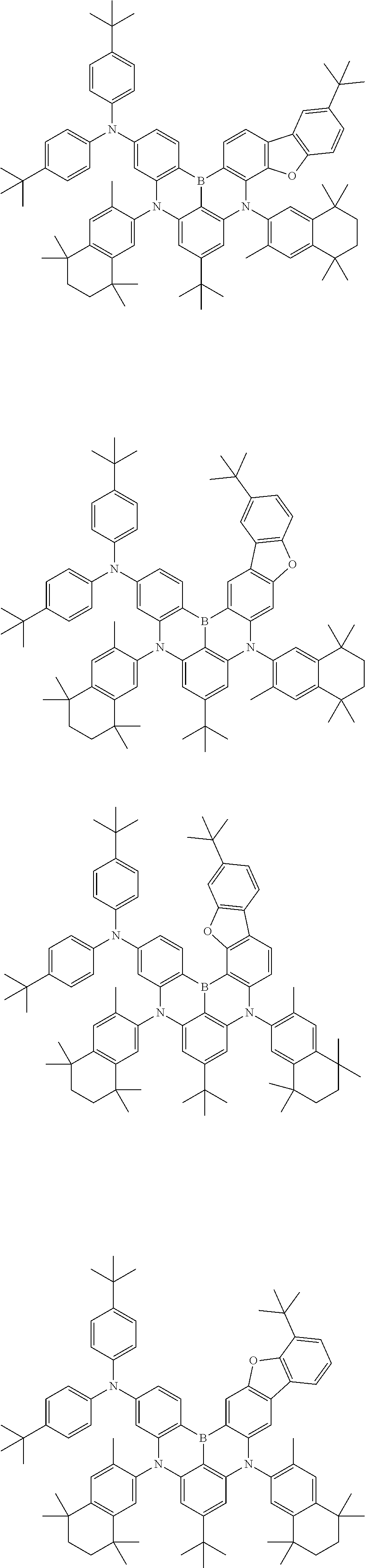

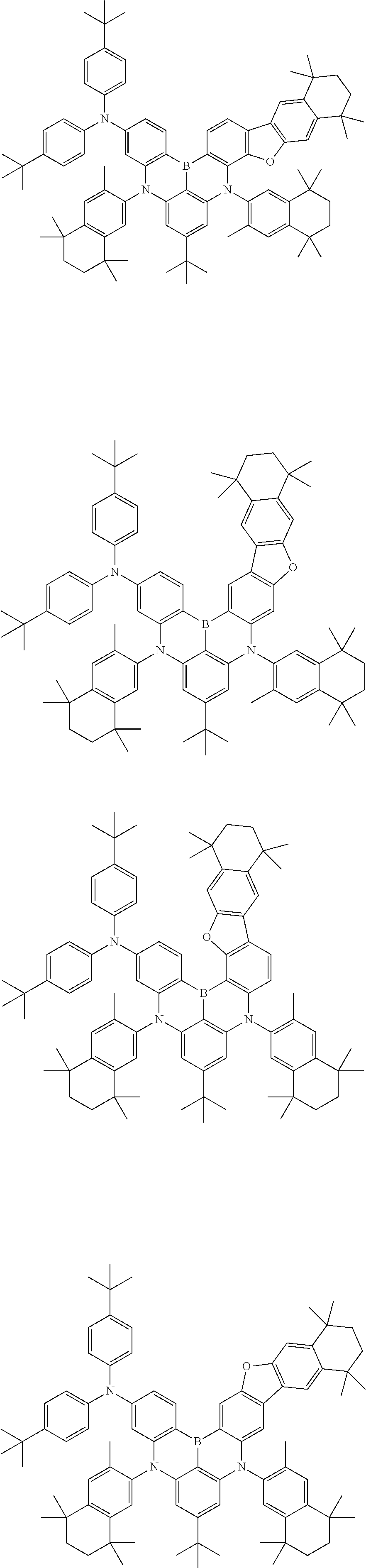

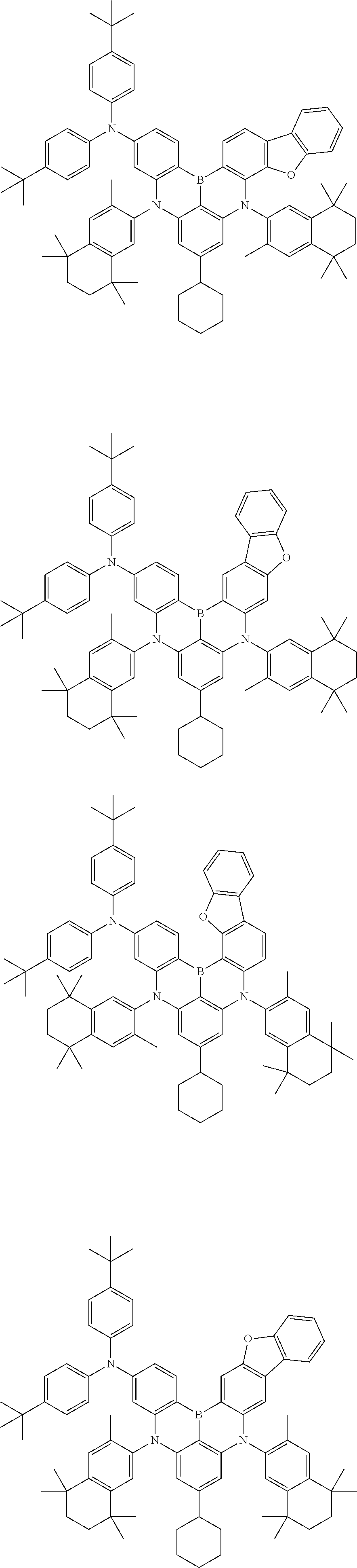

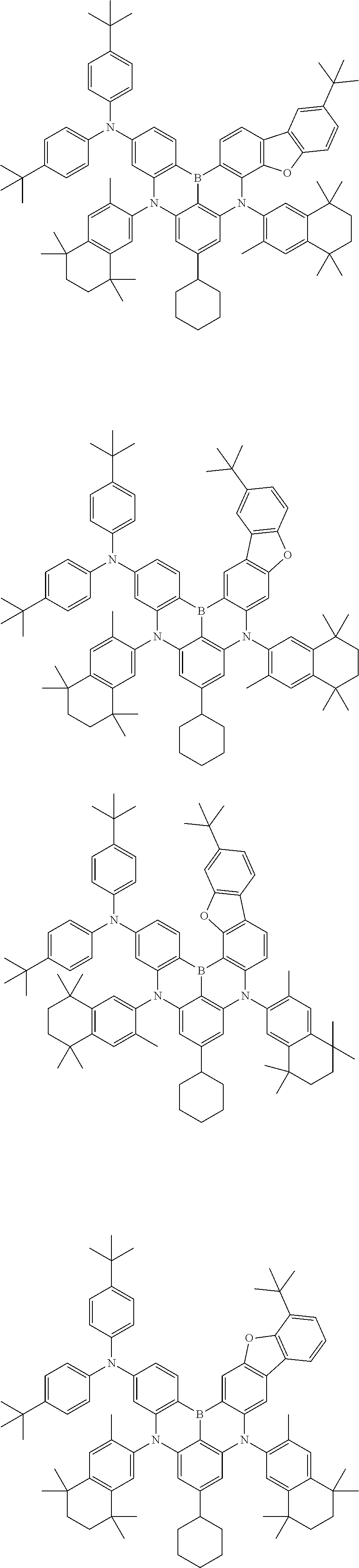

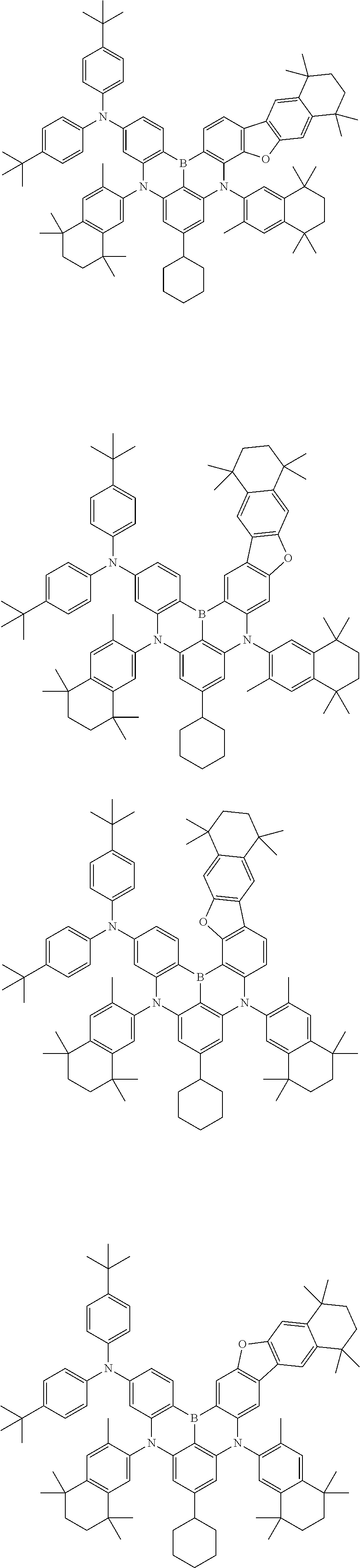

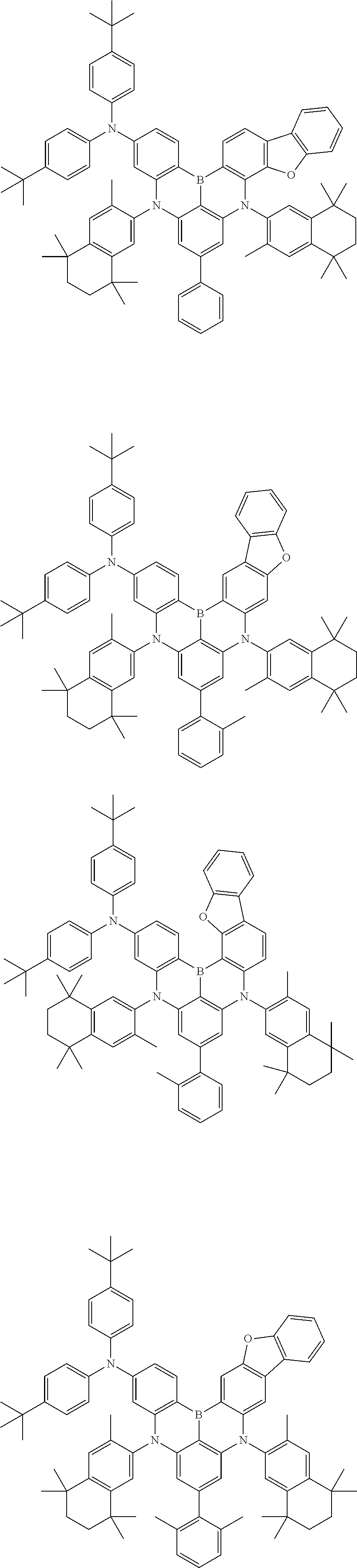

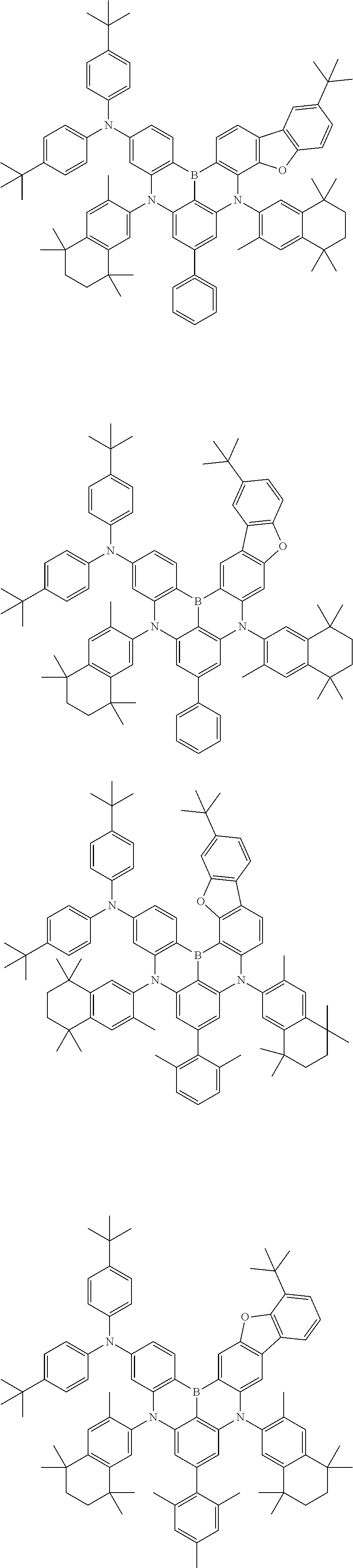

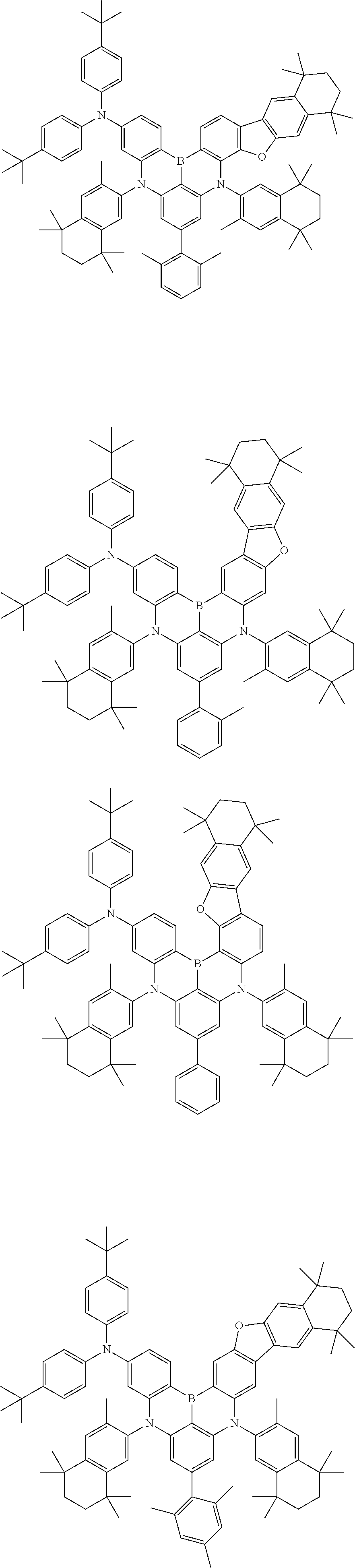

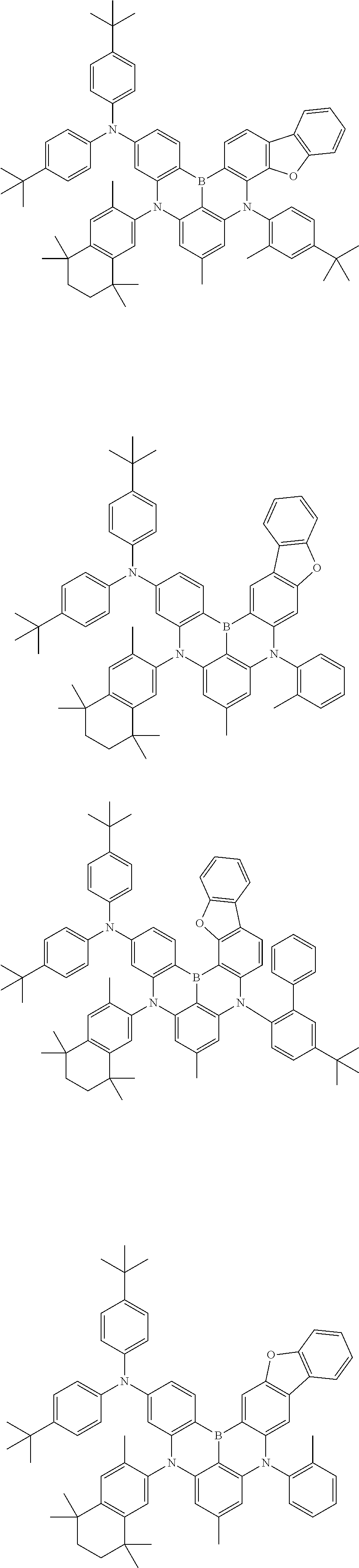

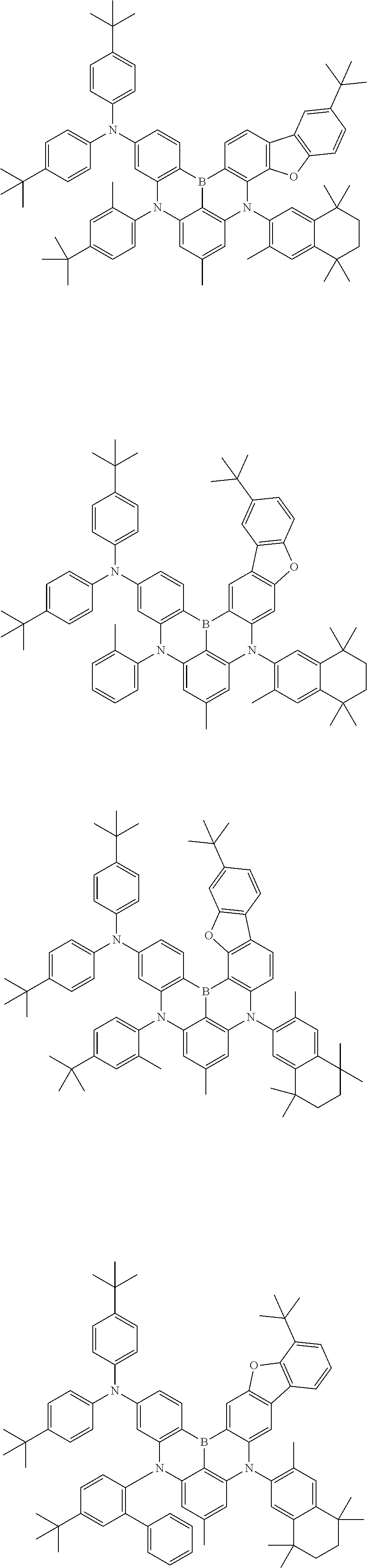

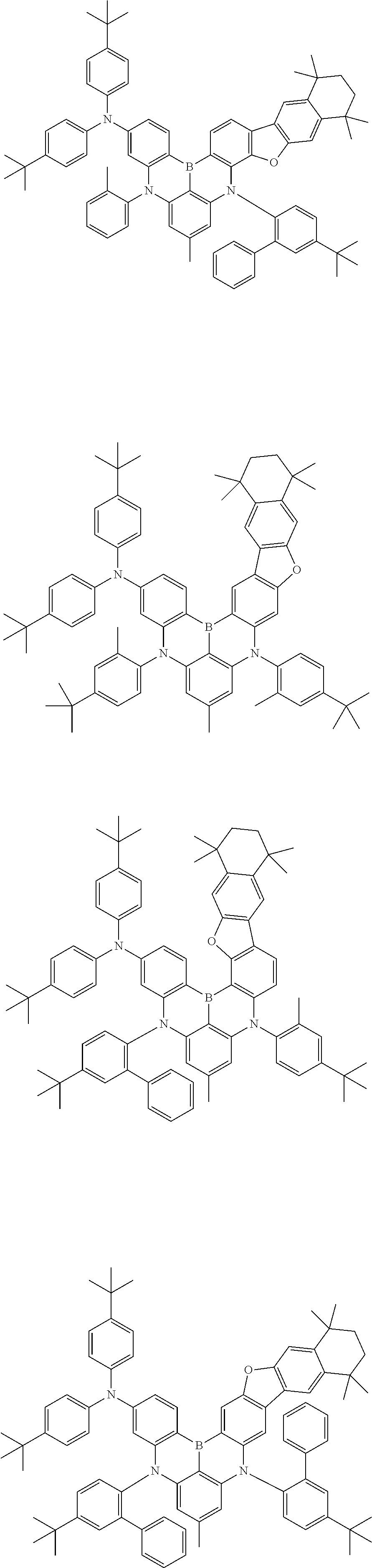

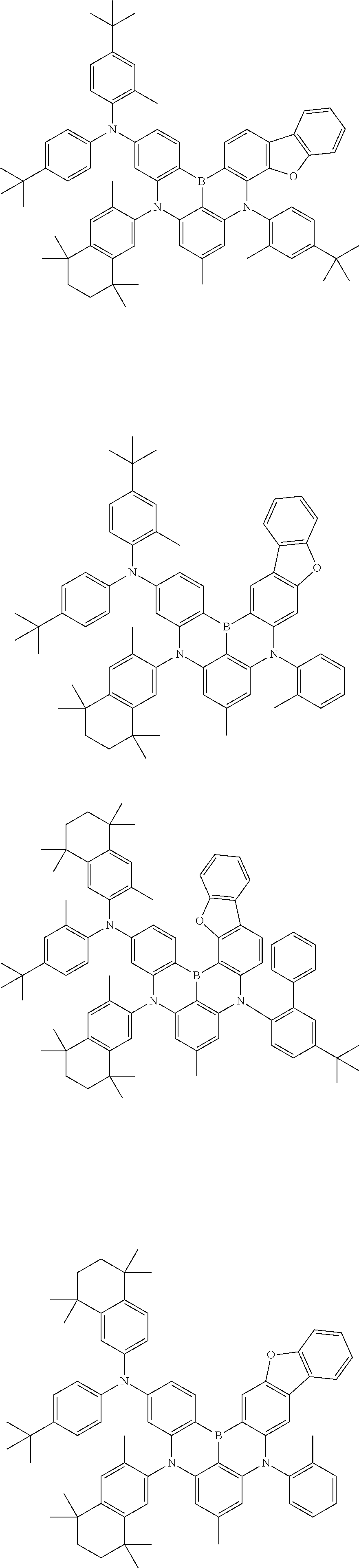

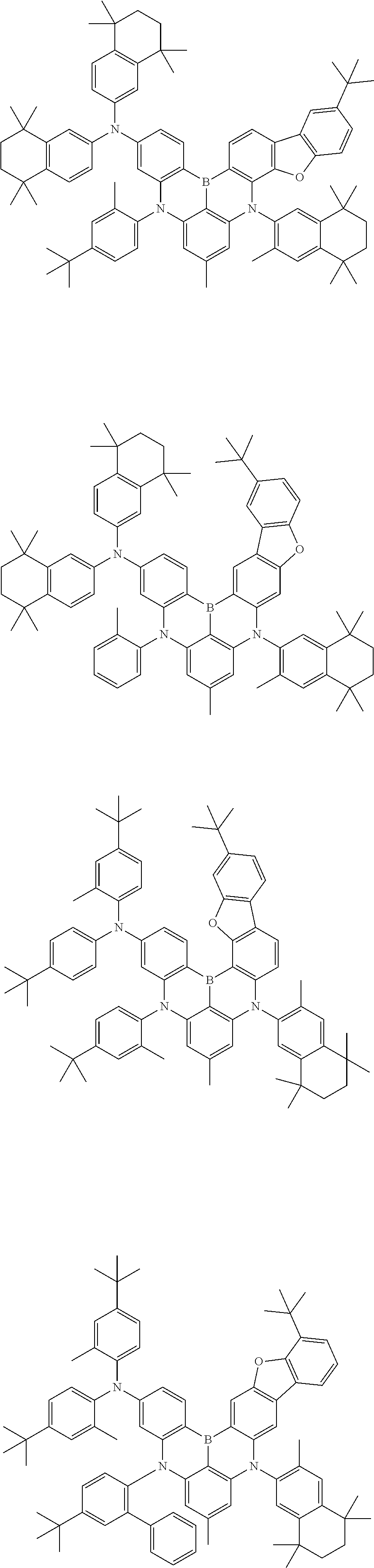

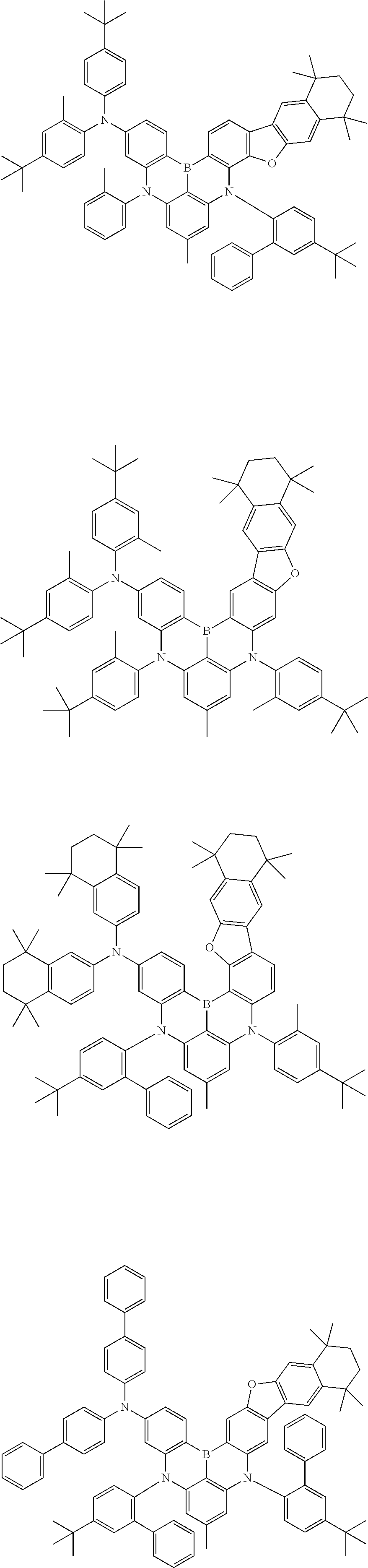

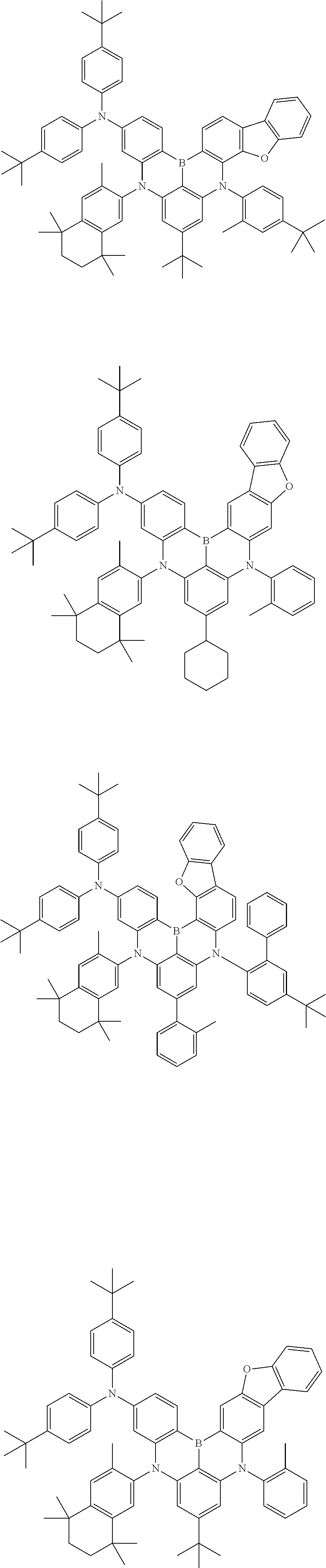

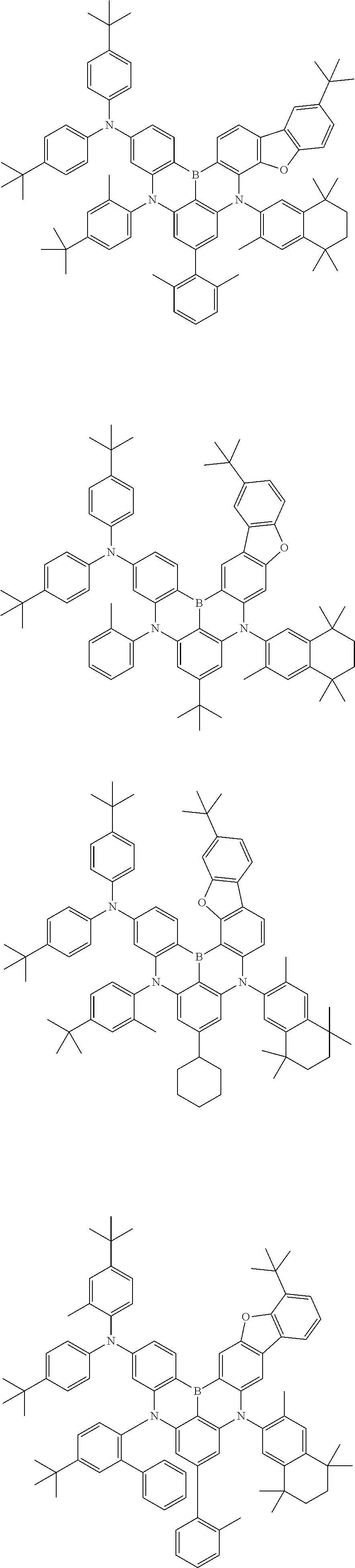

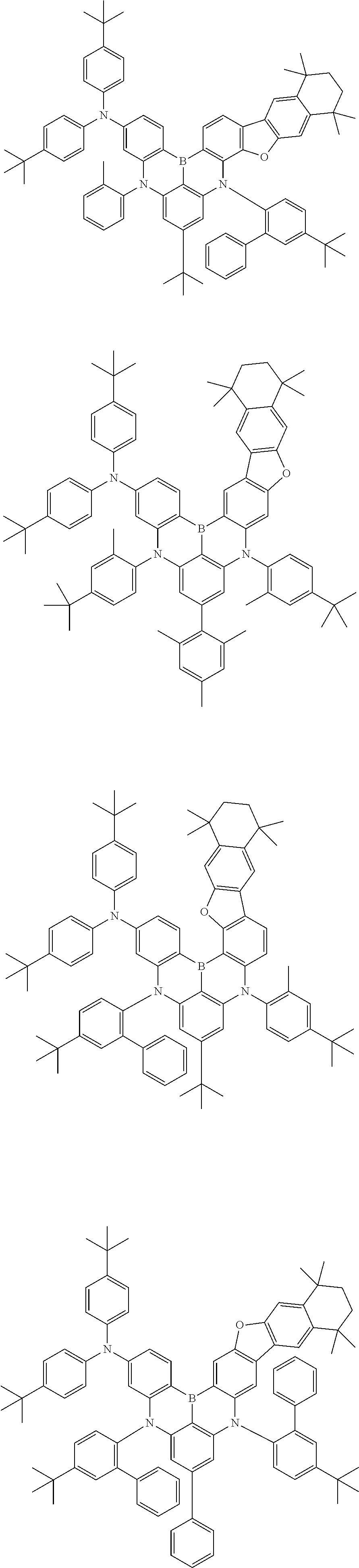

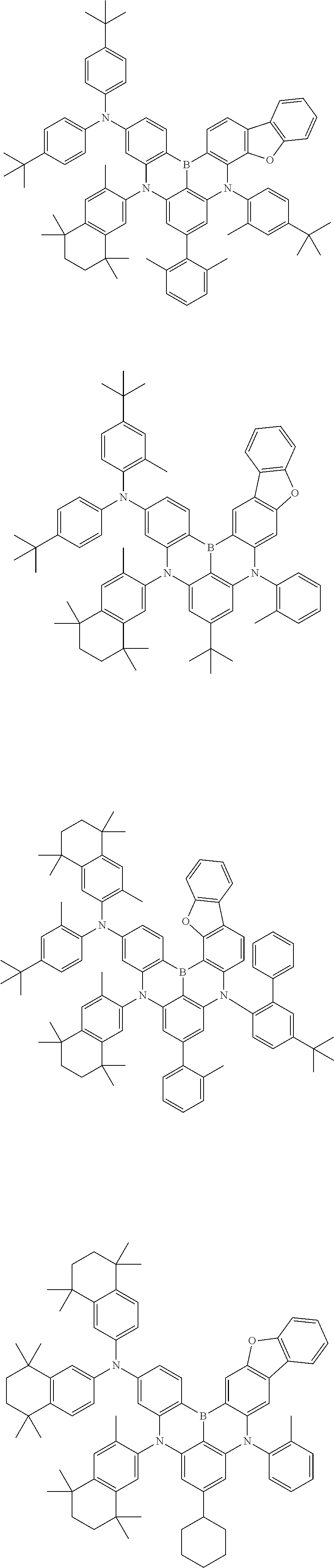

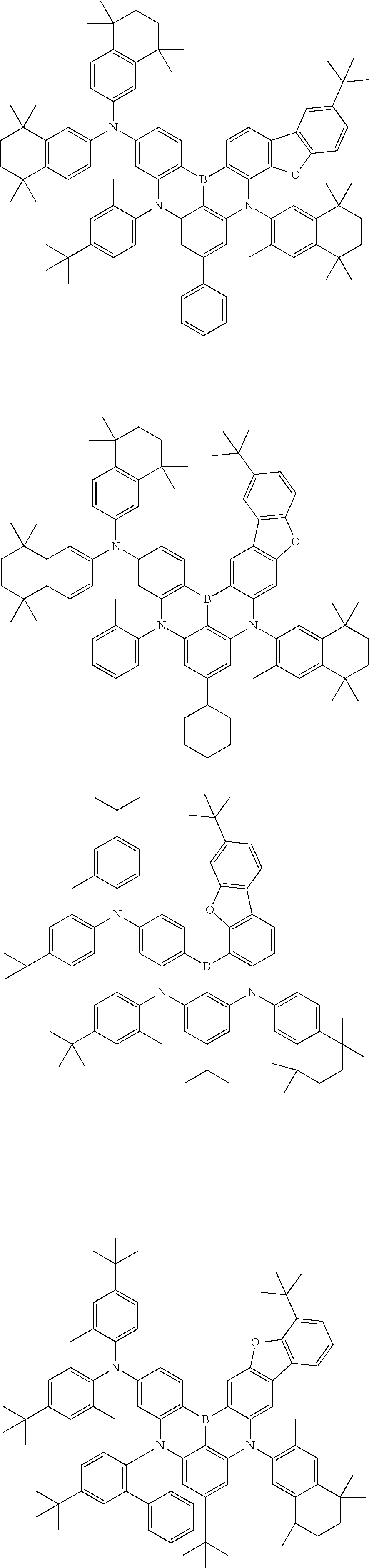

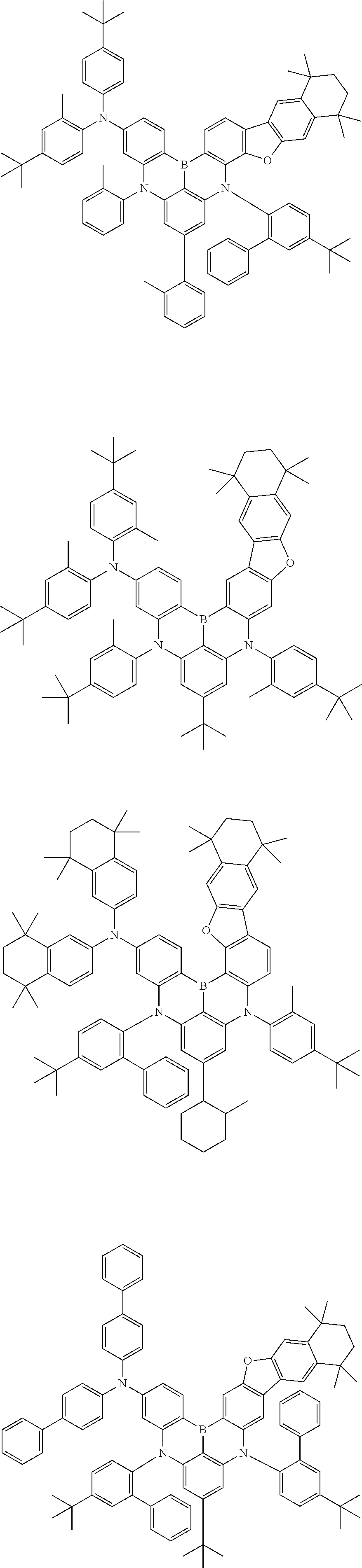

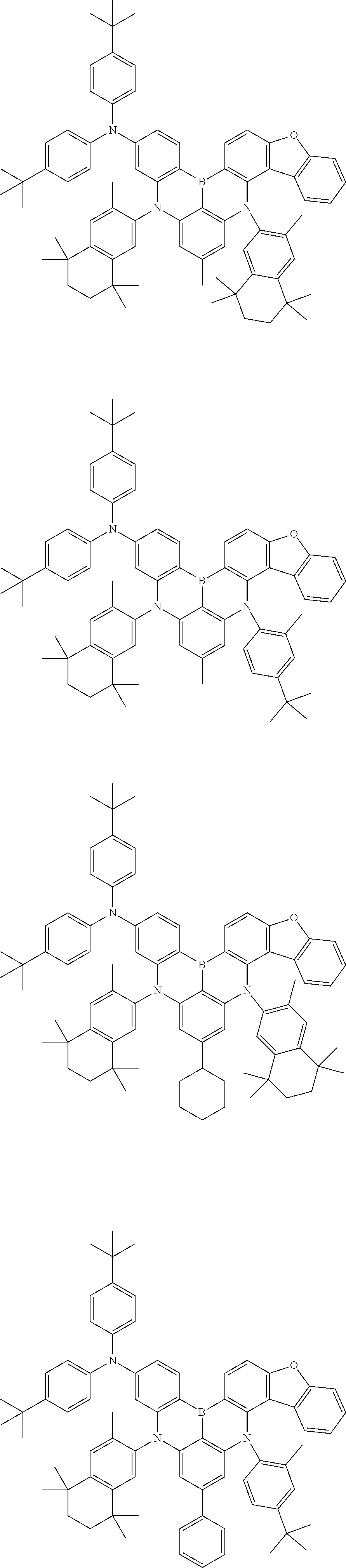

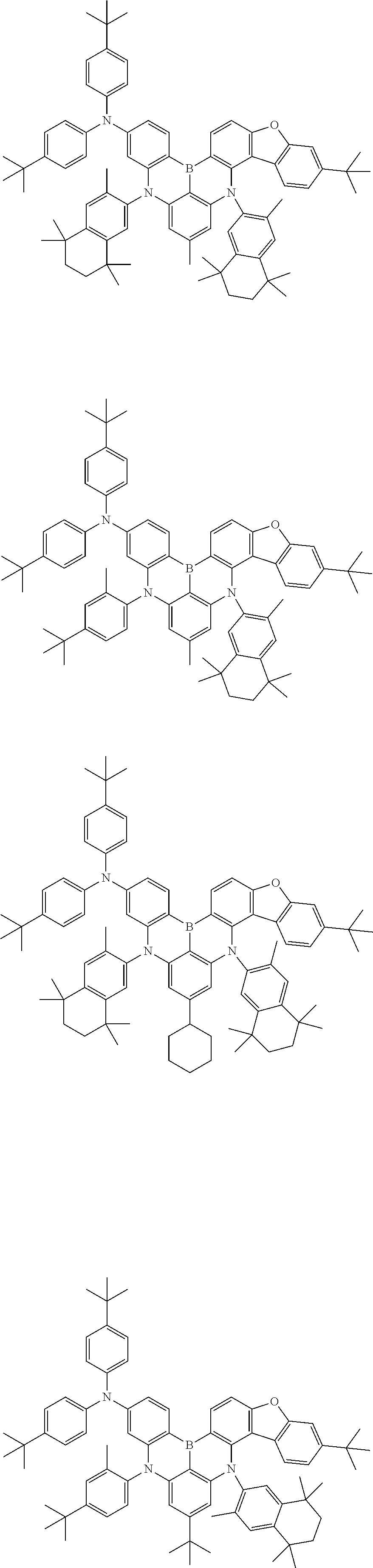

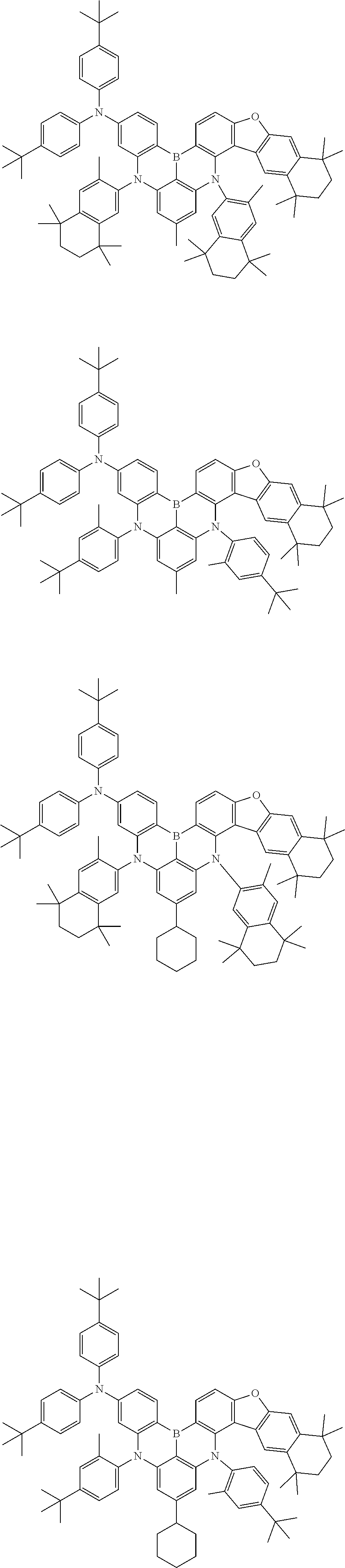

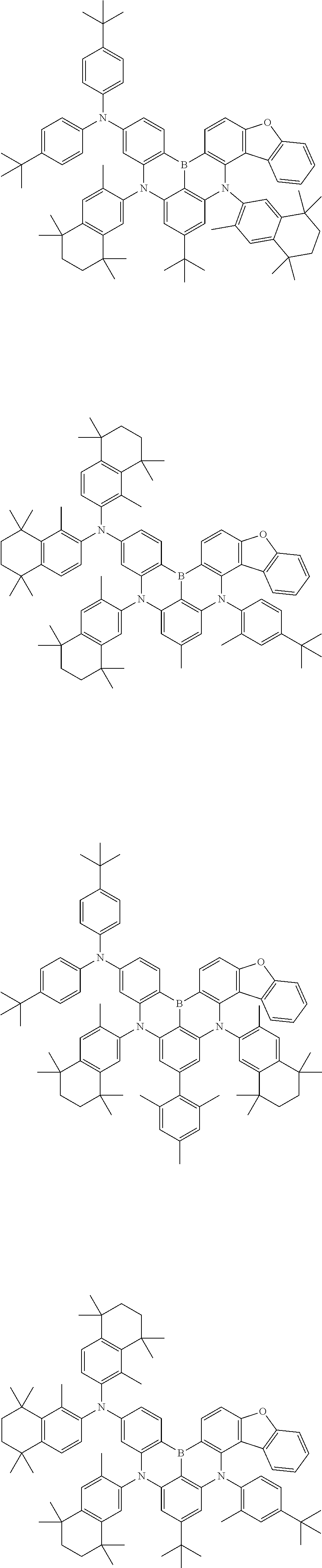

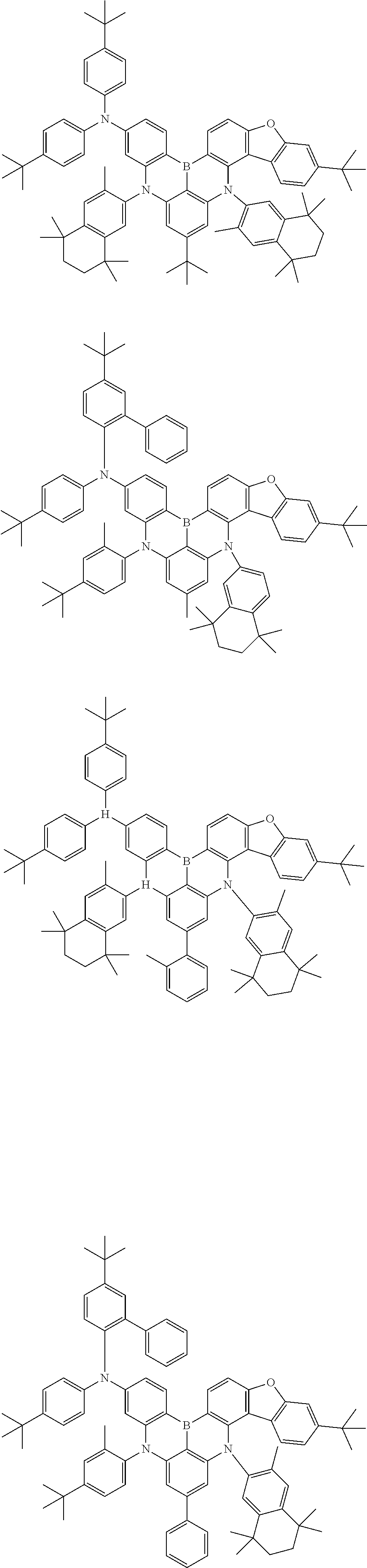

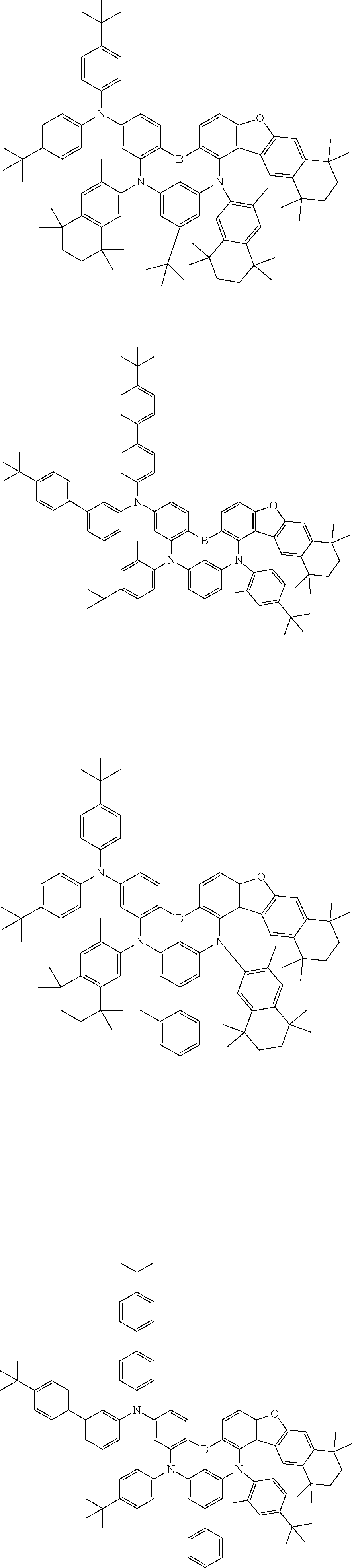

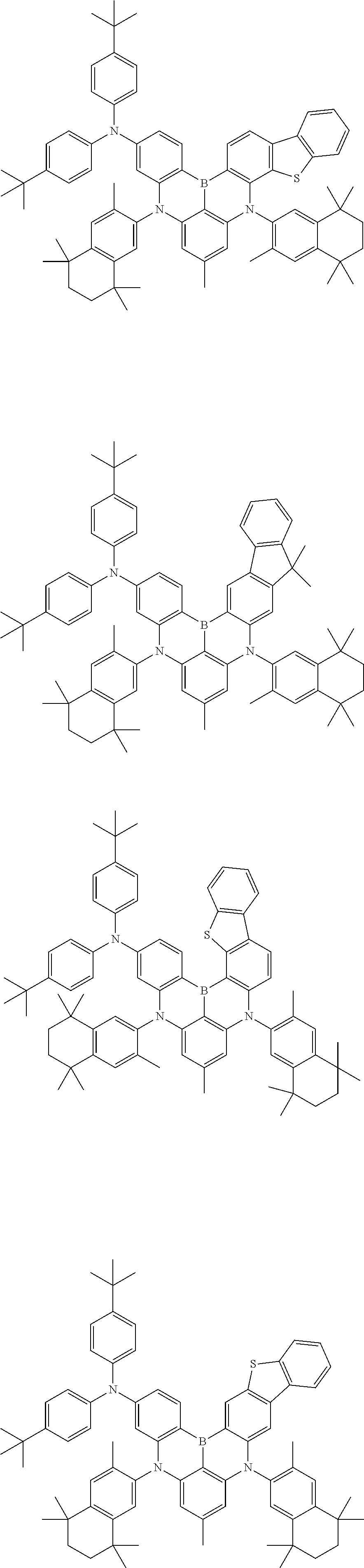

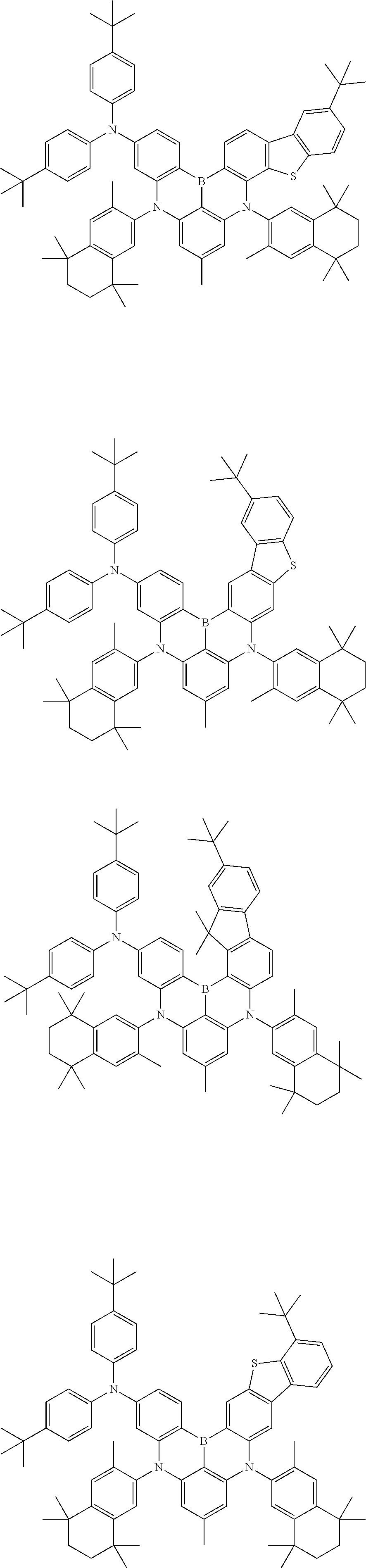

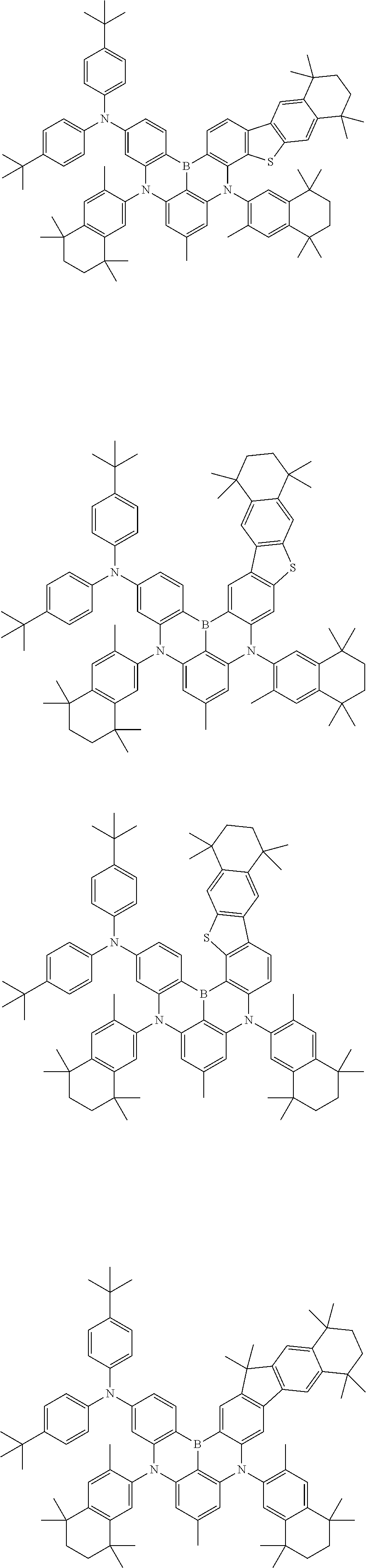

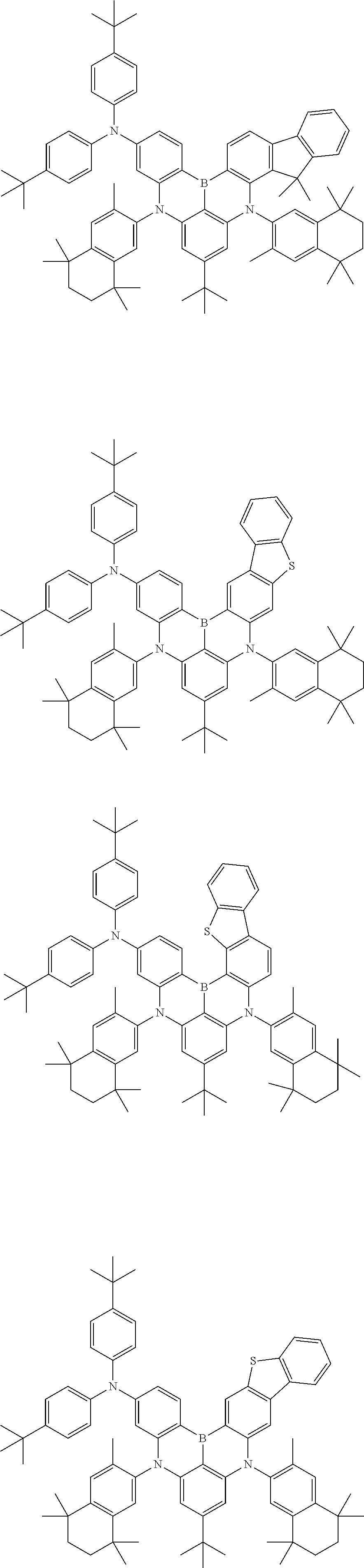

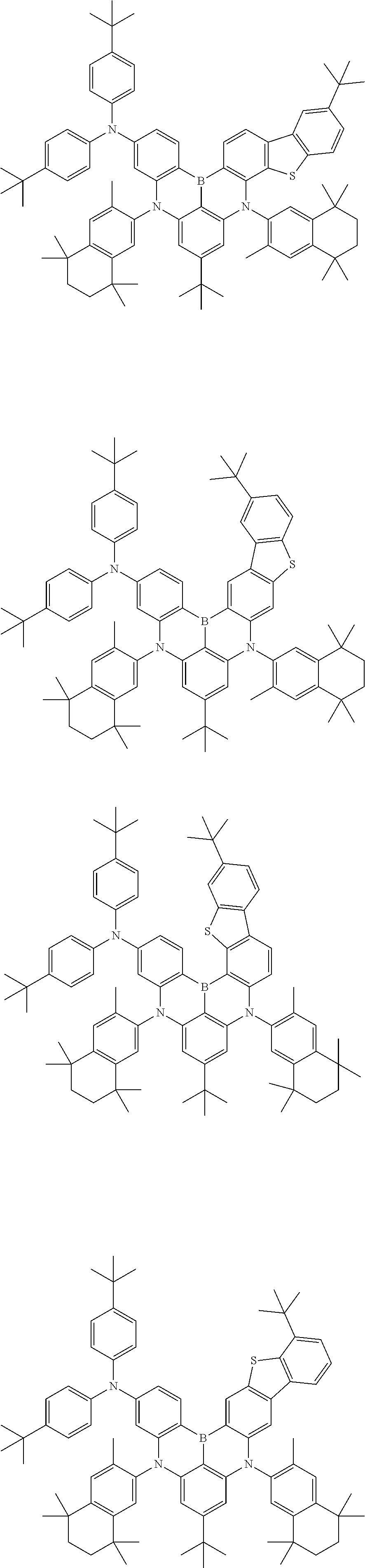

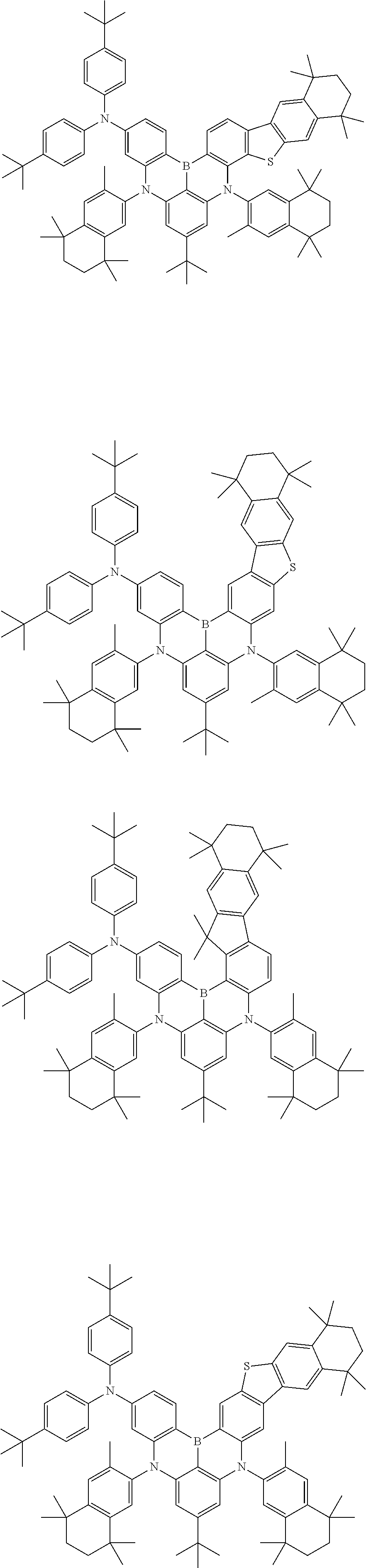

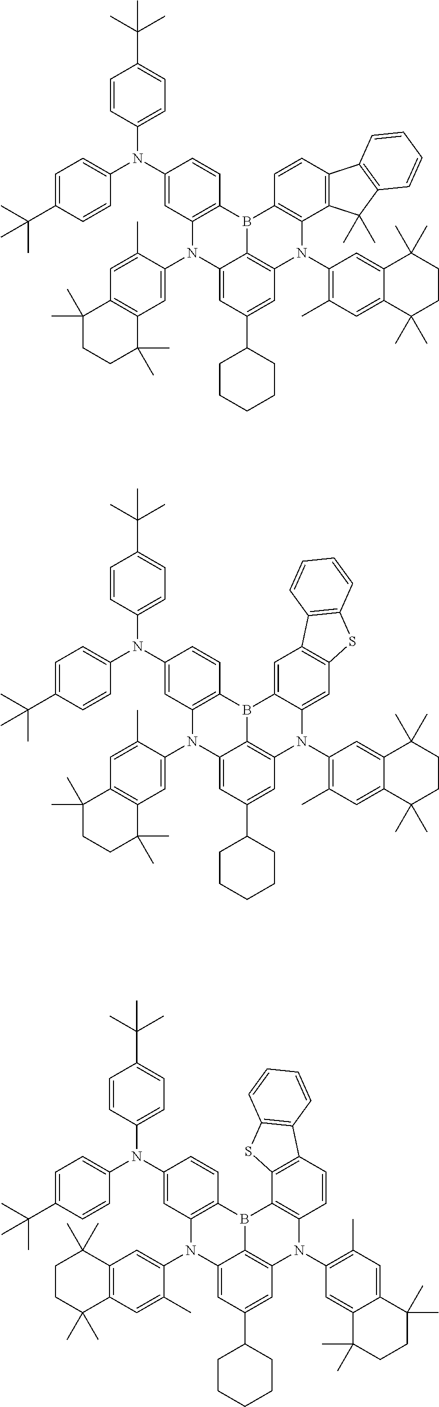 [SMILES: Cc1cc2c(cc1N1c3cc(N(c4ccc(C(C)(C)C)cc4)c4ccc(C(C)(C)C)cc4)ccc3B3c4ccc5c(c4N(c4cc6c(cc4C)C(C)(C)CCC6(C)C)c4cc(C6CCCCC6)cc1c43)C(C)(C)c1ccccc1-5)C(C)(C)CCC2(C)C ; Cc1cc2c(cc1N1c3cc(N(c4ccc(C(C)(C)C)cc4)c4ccc(C(C)(C)C)cc4)ccc3B3c4cc5c(cc4N(c4cc6c(cc4C)C(C)(C)CCC6(C)C)c4cc(C6CCCCC6)cc1c43)sc1ccccc15)C(C)(C)CCC2(C)C ; Cc1cc2c(cc1N1c3cc(N(c4ccc(C(C)(C)C)cc4)c4ccc(C(C)(C)C)cc4)ccc3B3c4c1cc(C1CCCCC1)cc4N(c1cc4c(cc1C)C(C)(C)CCC4(C)C)c1ccc4c(sc5ccccc54)c13)C(C)(C)CCC2(C)C]

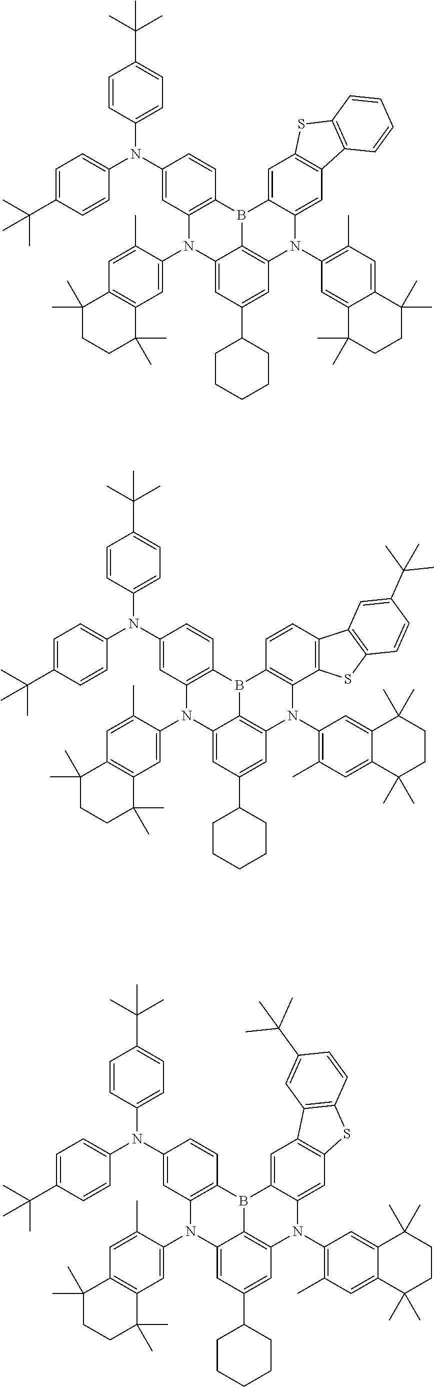

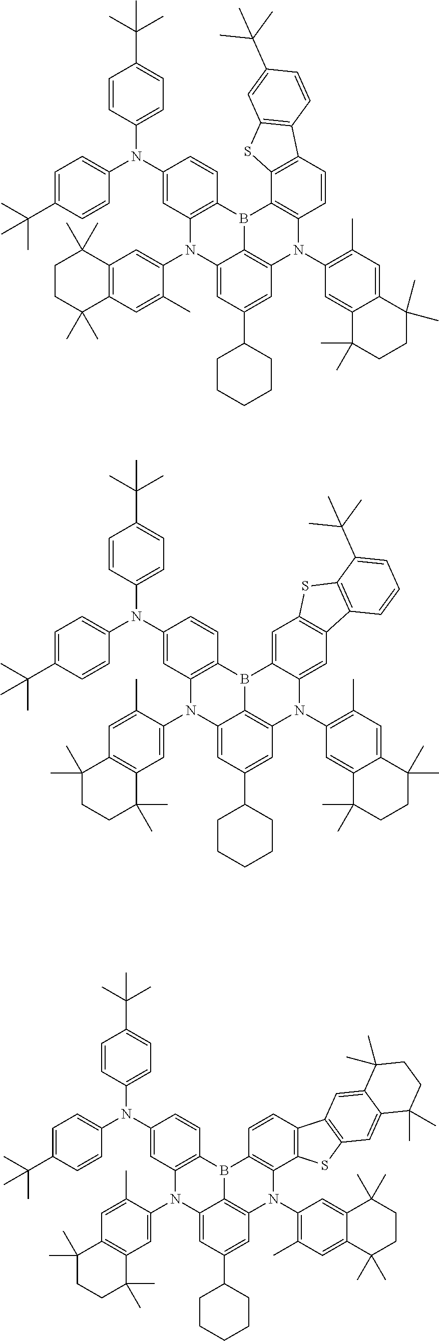

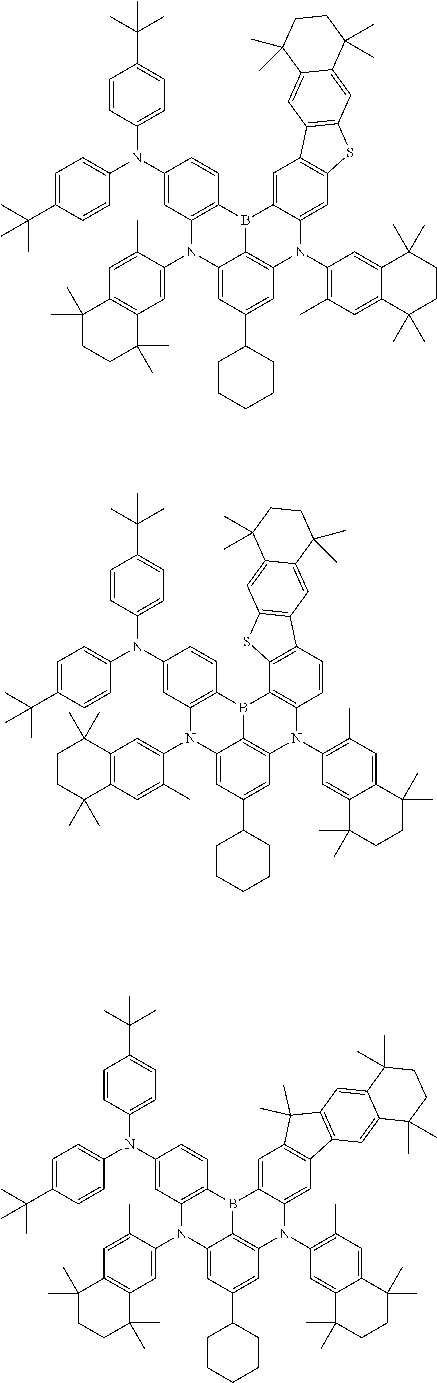

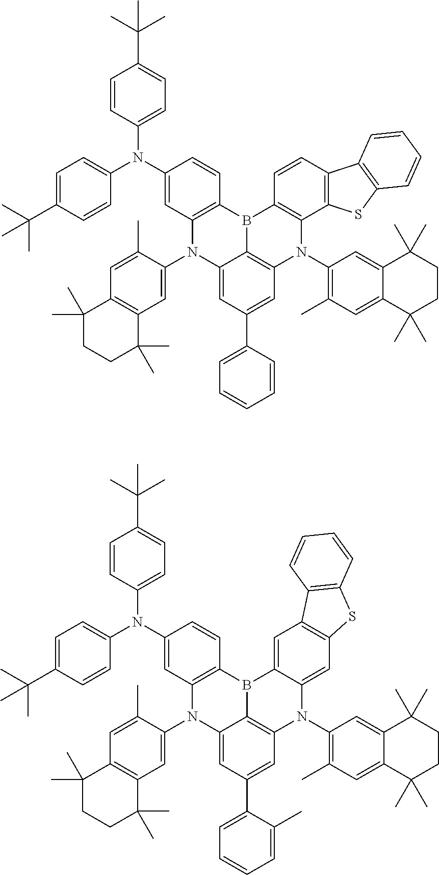 [SMILES: Cc1cc2c(cc1N1c3cc(N(c4ccc(C(C)(C)C)cc4)c4ccc(C(C)(C)C)cc4)ccc3B3c4ccc5c(sc6ccccc65)c4N(c4cc5c(cc4C)C(C)(C)CCC5(C)C)c4cc(-c5ccccc5)cc1c43)C(C)(C)CCC2(C)C ; Cc1ccccc1-c1cc2c3c(c1)N(c1cc4c(cc1C)C(C)(C)CCC4(C)C)c1cc4sc5ccccc5c4cc1B3c1ccc(N(c3ccc(C(C)(C)C)cc3)c3ccc(C(C)(C)C)cc3)cc1N2c1cc2c(cc1C)C(C)(C)CCC2(C)C]

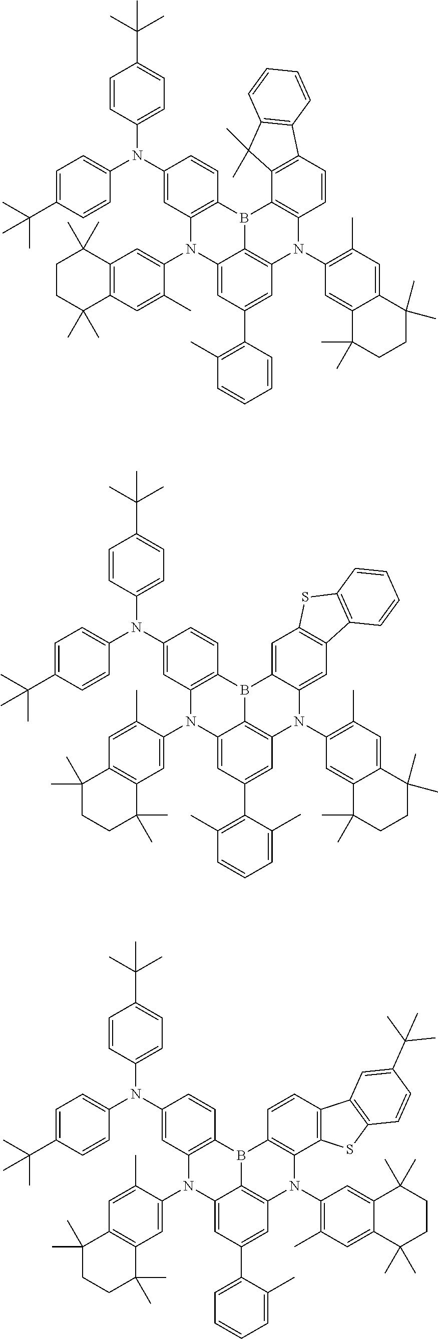

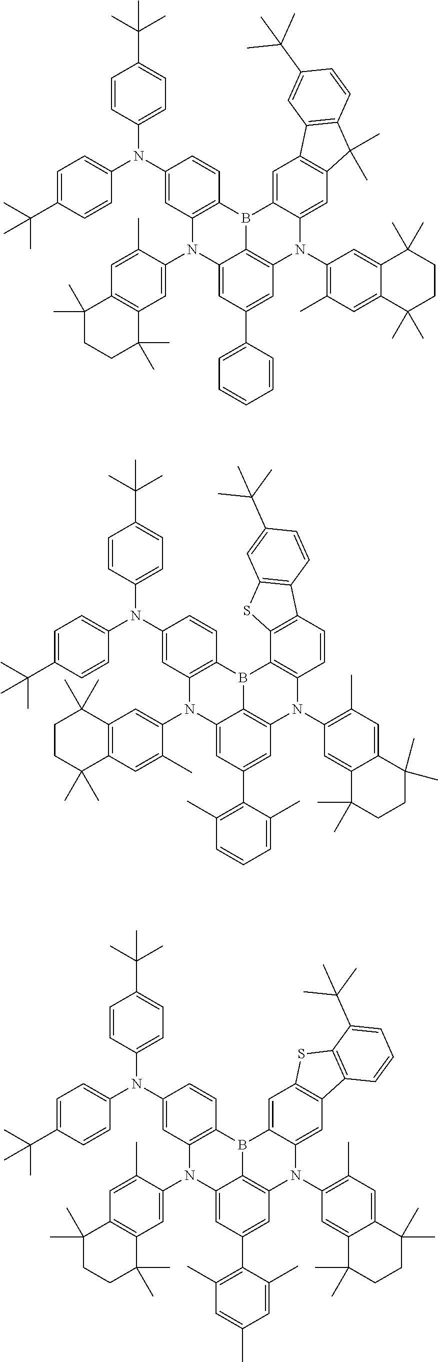

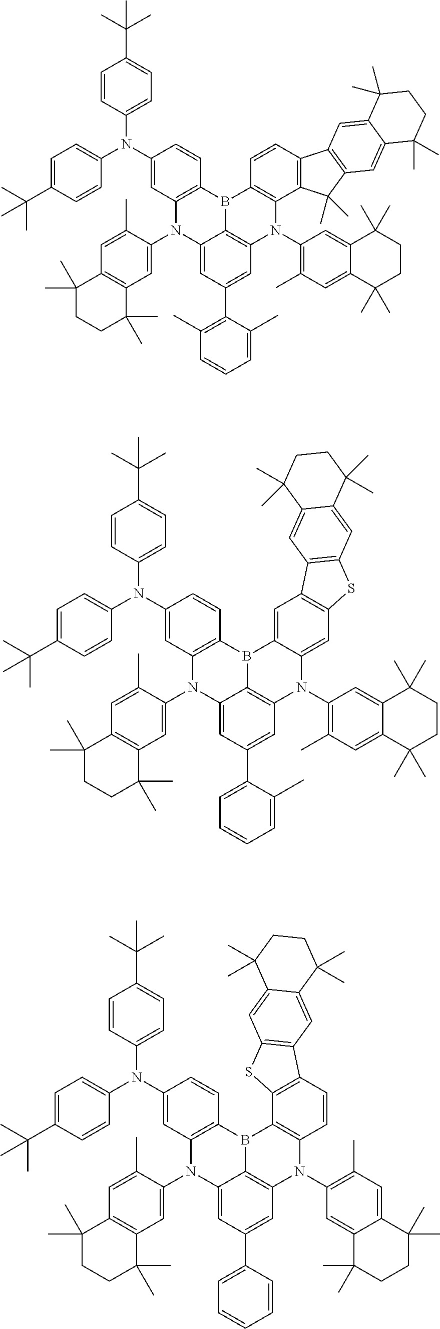

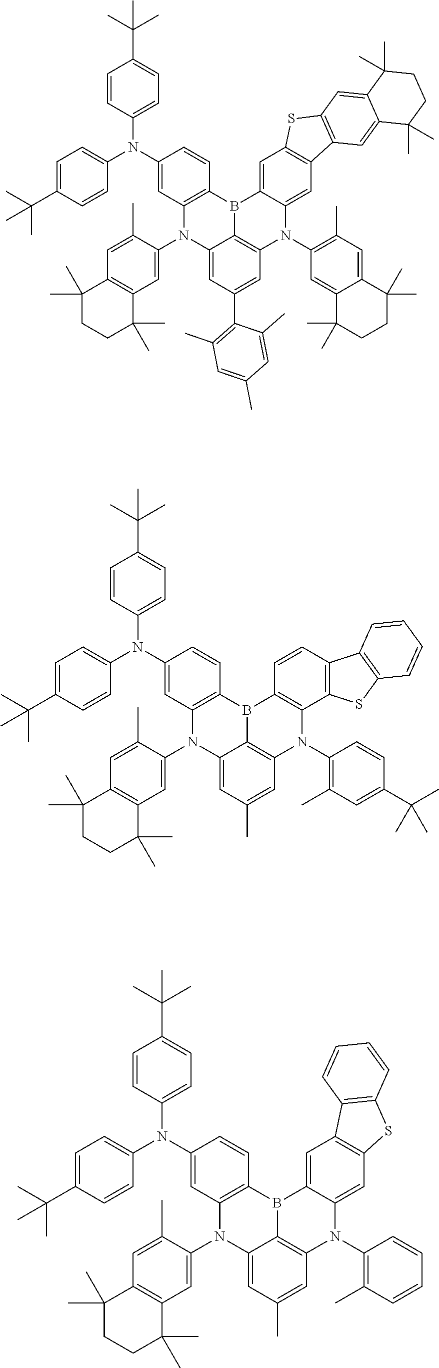

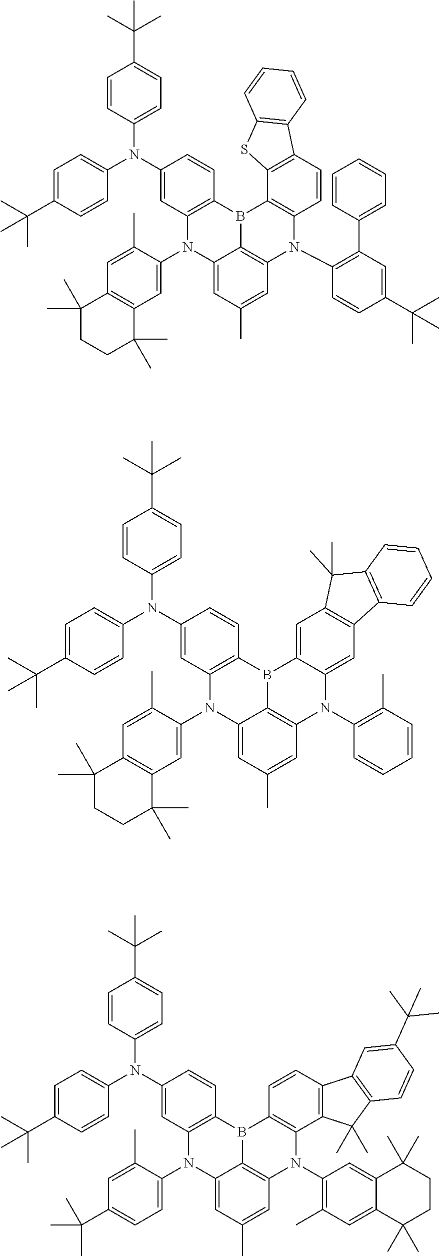

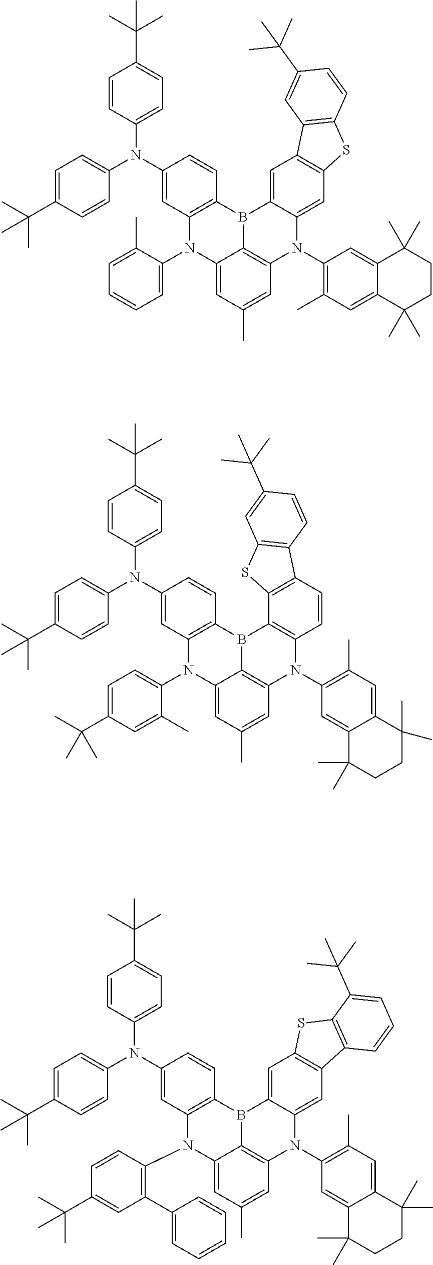

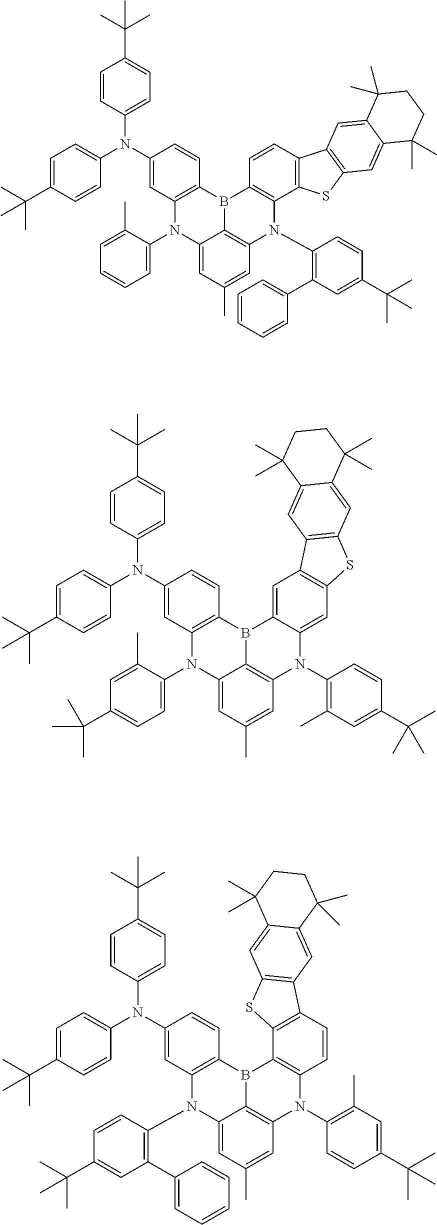

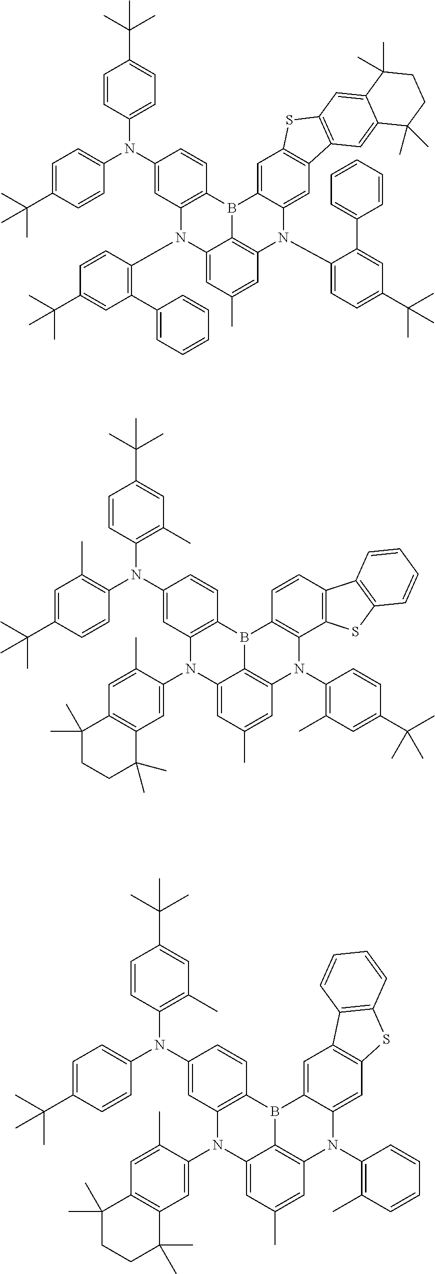

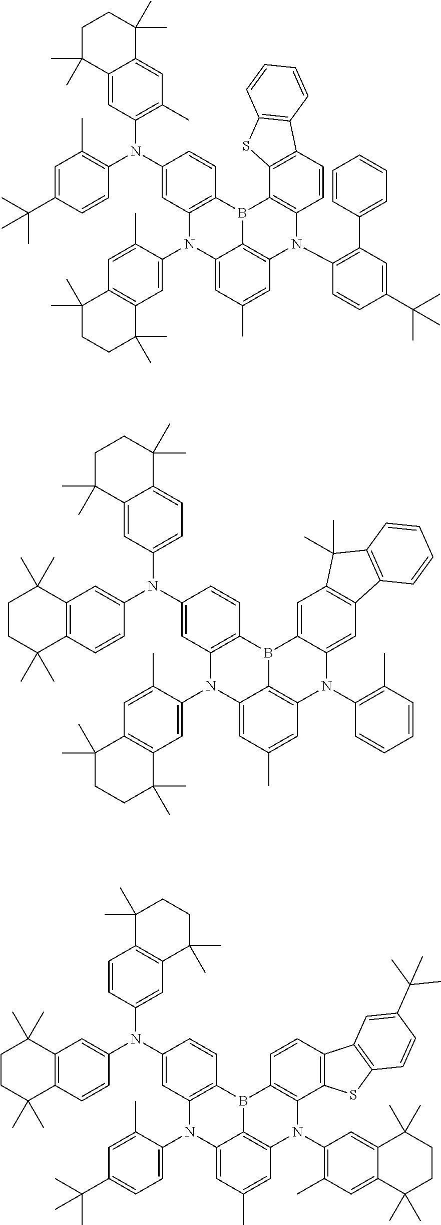 [SMILES: Cc1cc2c3c(c1)N(c1ccc(C(C)(C)C)cc1-c1ccccc1)c1ccc4c(sc5ccccc54)c1B3c1ccc(N(c3ccc(C(C)(C)C)cc3C)c3cc4c(cc3C)C(C)(C)CCC4(C)C)cc1N2c1cc2c(cc1C)C(C)(C)CCC2(C)C ; Cc1cc2c3c(c1)N(c1ccccc1C)c1cc4c(cc1B3c1ccc(N(c3ccc5c(c3)C(C)(C)CCC5(C)C)c3ccc5c(c3)C(C)(C)CCC5(C)C)cc1N2c1cc2c(cc1C)C(C)(C)CCC2(C)C)C(C)(C)c1ccccc1-4 ; Cc1cc2c3c(c1)N(c1cc4c(cc1C)C(C)(C)CCC4(C)C)c1c(ccc4c1sc1ccc(C(C)(C)C)cc14)B3c1ccc(N(c3ccc4c(c3)C(C)(C)CCC4(C)C)c3ccc4c(c3)C(C)(C)CCC4(C)C)cc1N2c1ccc(C(C)(C)C)cc1C]

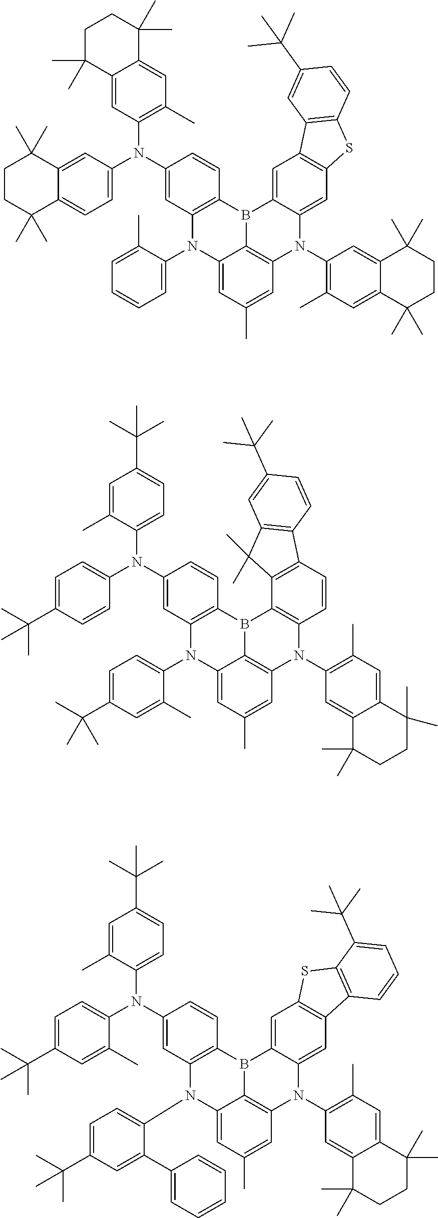

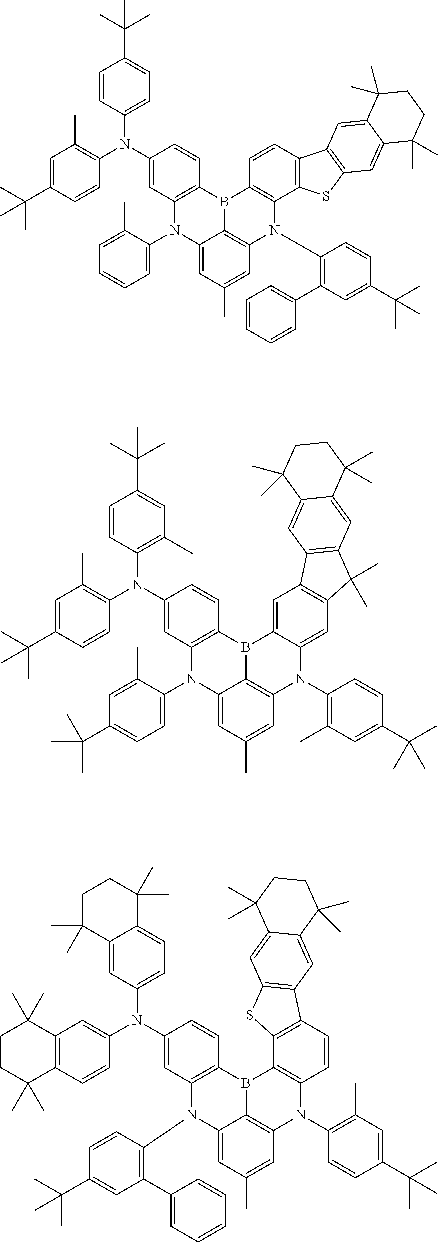

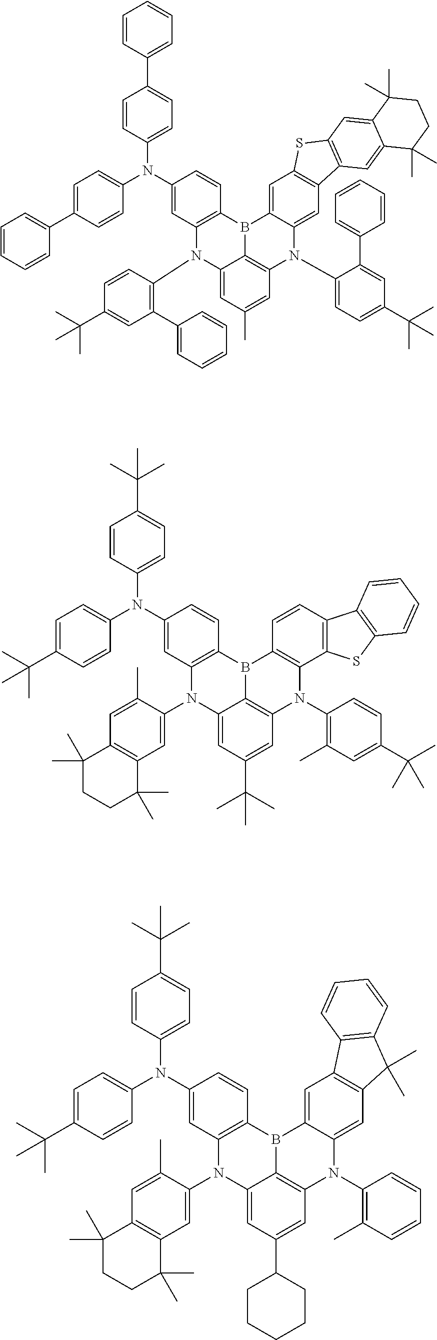

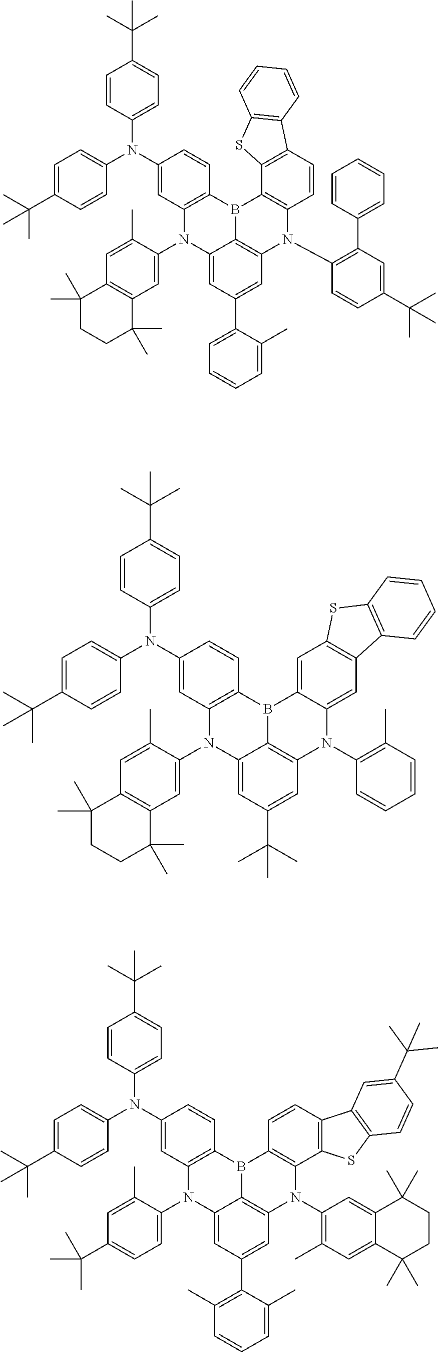

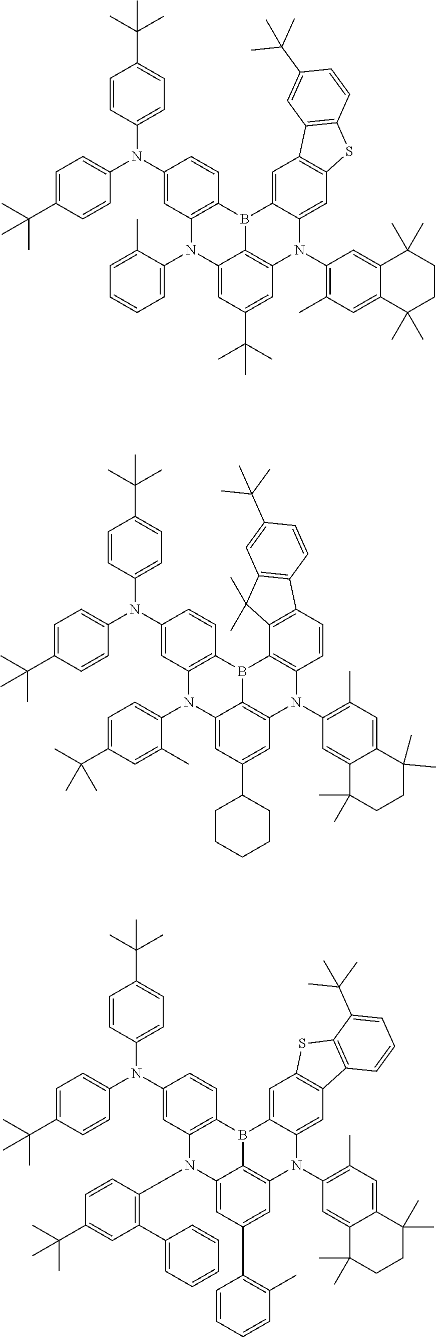

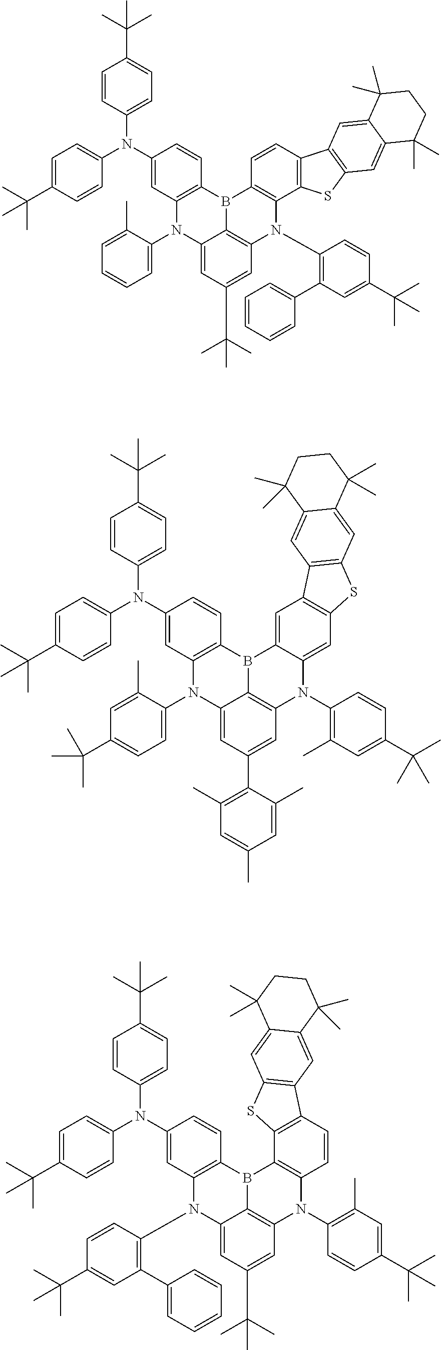

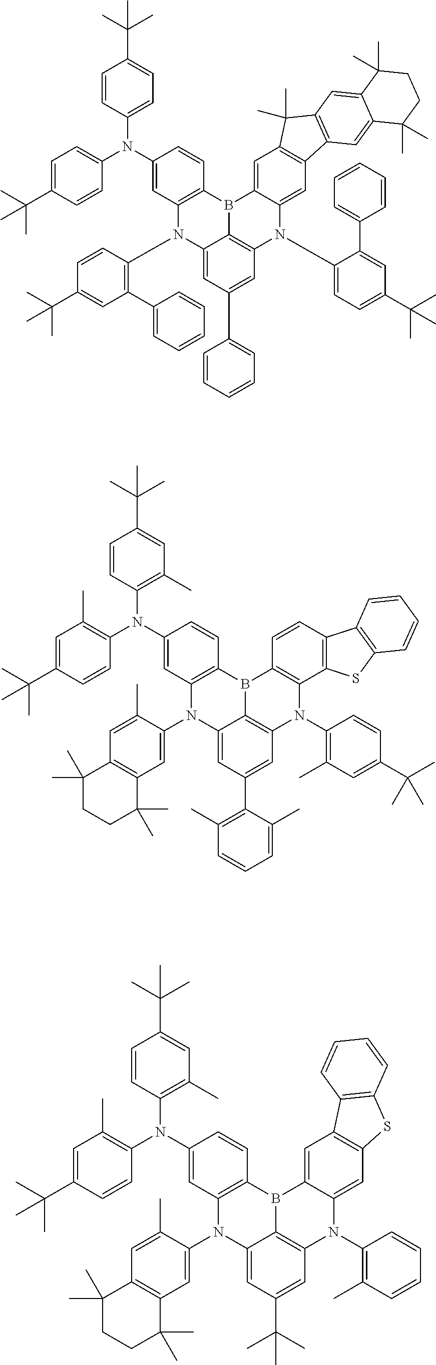

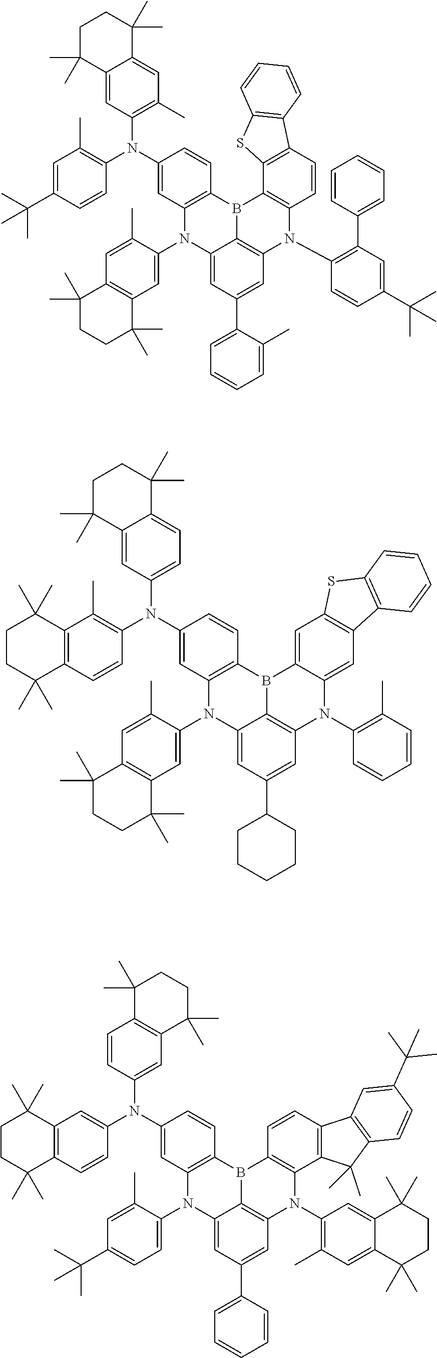 [SMILES: Cc1ccccc1-c1cc2c3c(c1)N(c1ccc(C(C)(C)C)cc1-c1ccccc1)c1ccc4c(sc5ccccc54)c1B3c1ccc(N(c3ccc(C(C)(C)C)cc3C)c3cc4c(cc3C)C(C)(C)CCC4(C)C)cc1N2c1cc2c(cc1C)C(C)(C)CCC2(C)C ; Cc1ccccc1N1c2cc3c(cc2B2c4ccc(N(c5ccc6c(c5)C(C)(C)CCC6(C)C)c5ccc6c(c5C)C(C)(C)CCC6(C)C)cc4N(c4cc5c(cc4C)C(C)(C)CCC5(C)C)c4cc(C5CCCCC5)cc1c42)sc1ccccc13 ; Cc1cc(C(C)(C)C)ccc1N1c2cc(N(c3ccc4c(c3)C(C)(C)CCC4(C)C)c3ccc4c(c3)C(C)(C)CCC4(C)C)ccc2B2c3ccc4c(c3N(c3cc5c(cc3C)C(C)(C)CCC5(C)C)c3cc(-c5ccccc5)cc1c32)C(C)(C)c1ccc(C(C)(C)C)cc1-4]

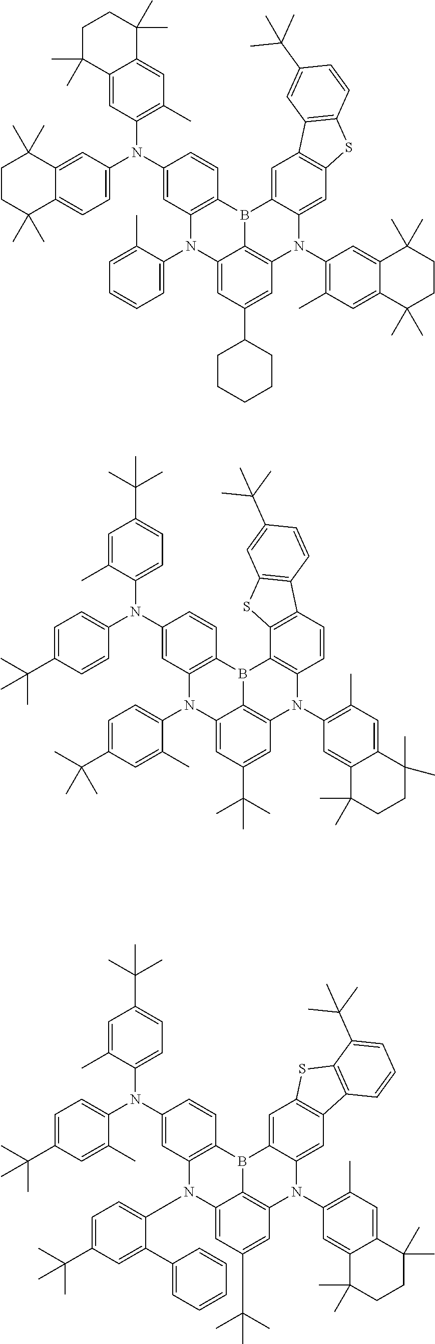

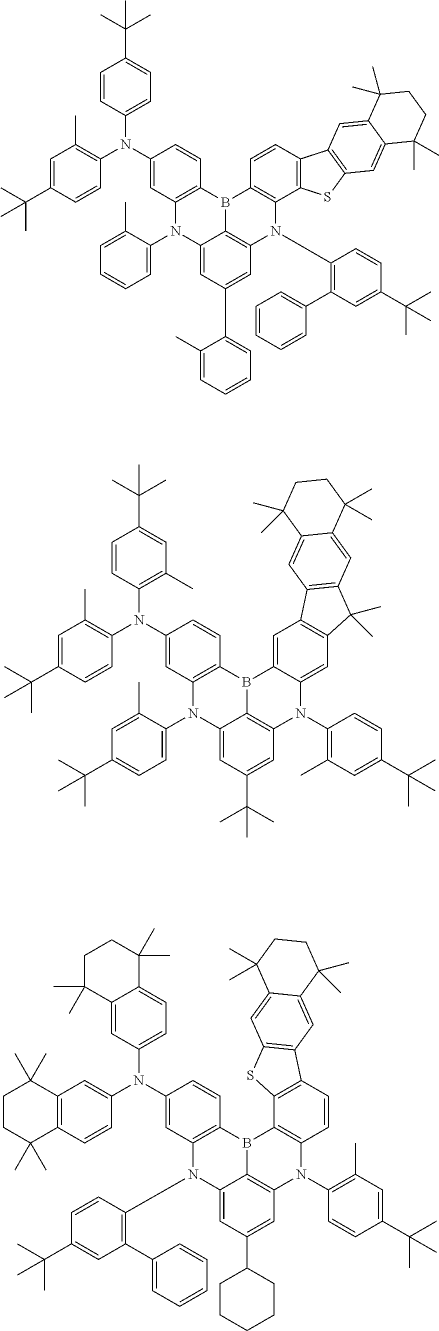

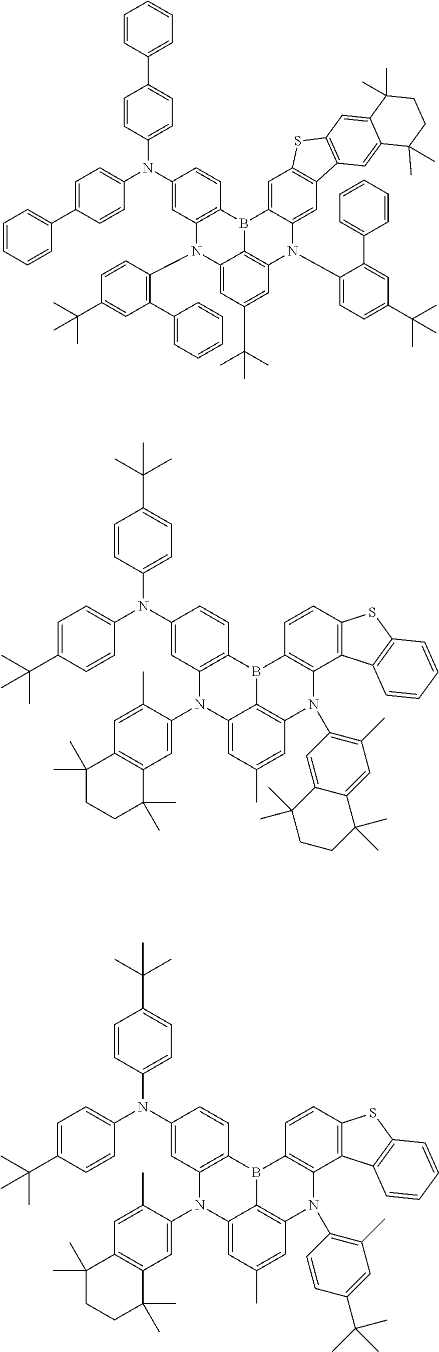

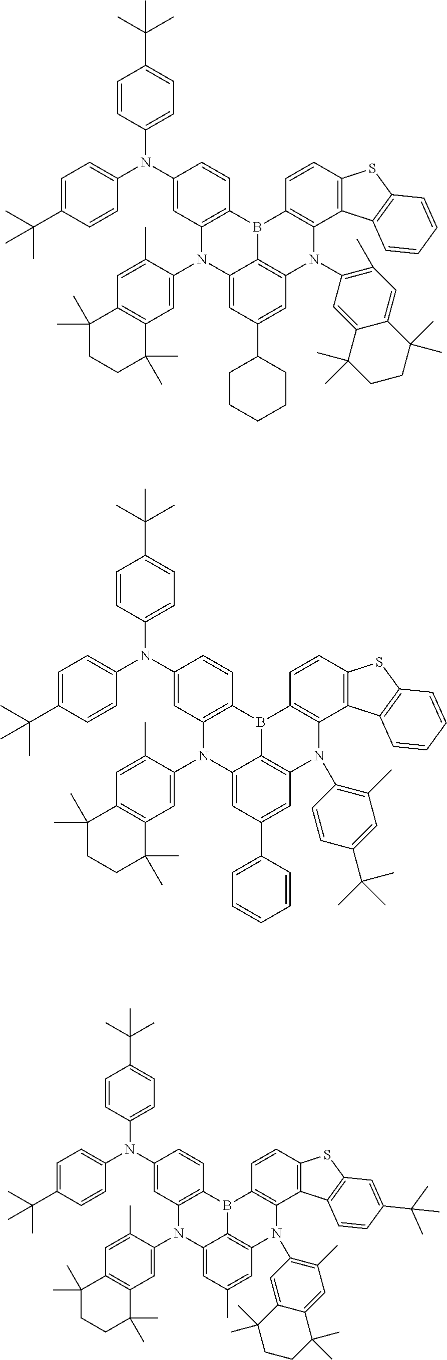

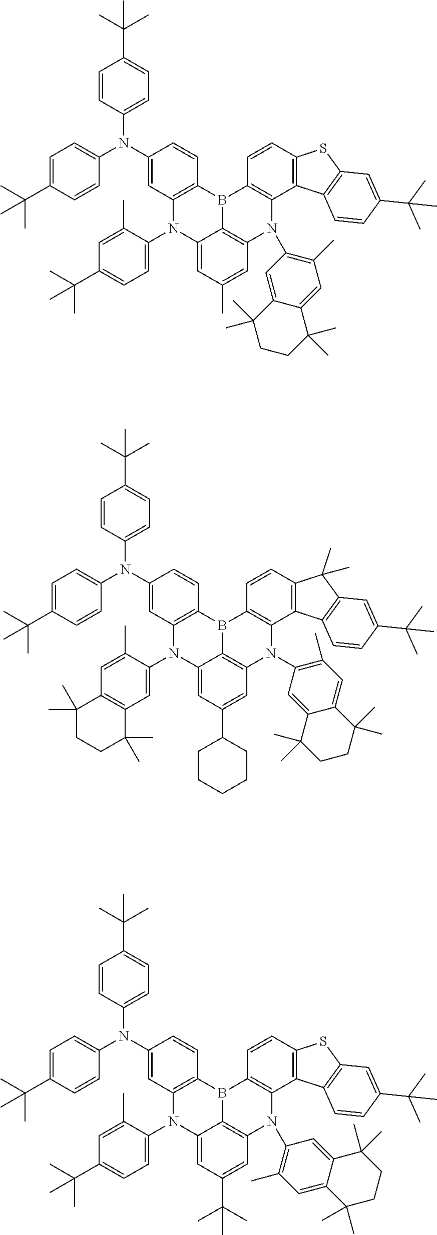

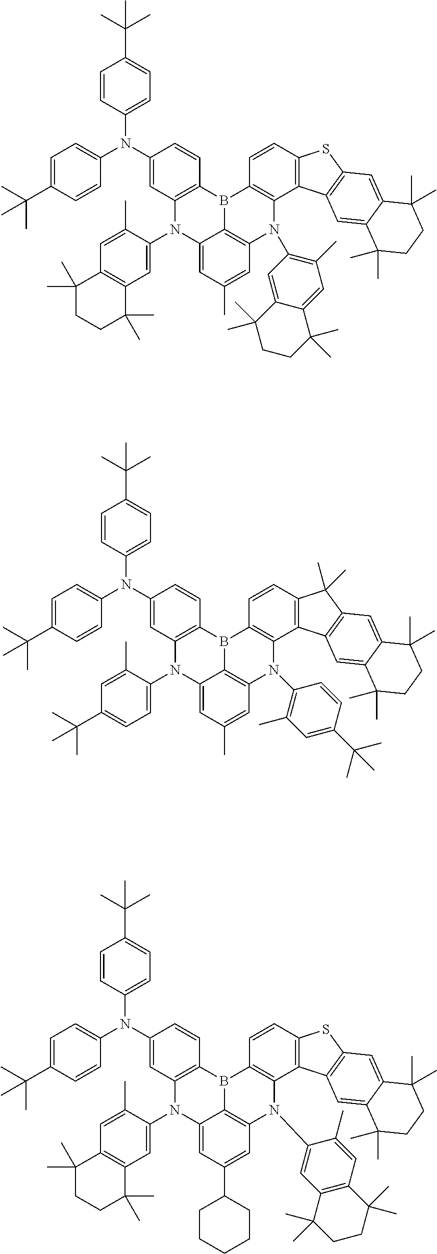

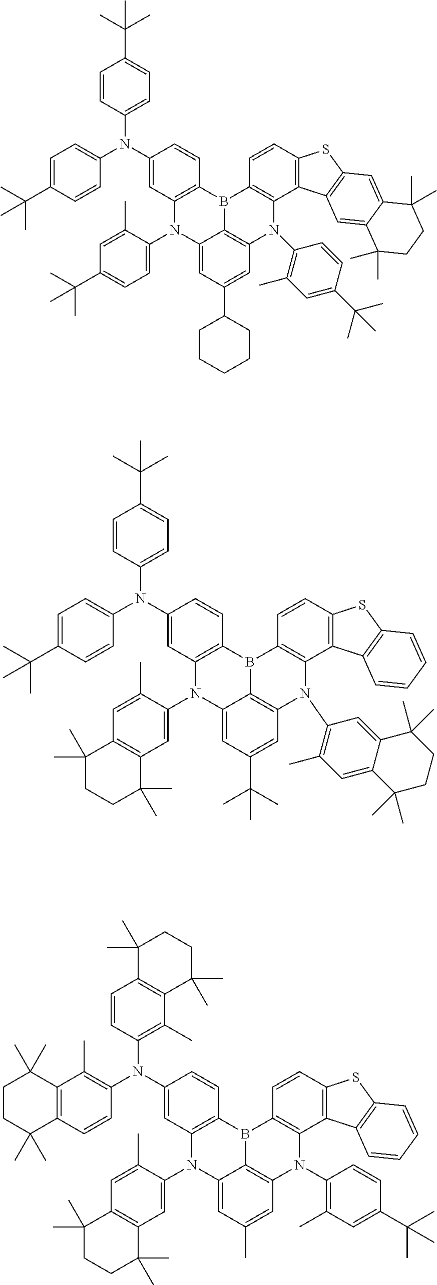

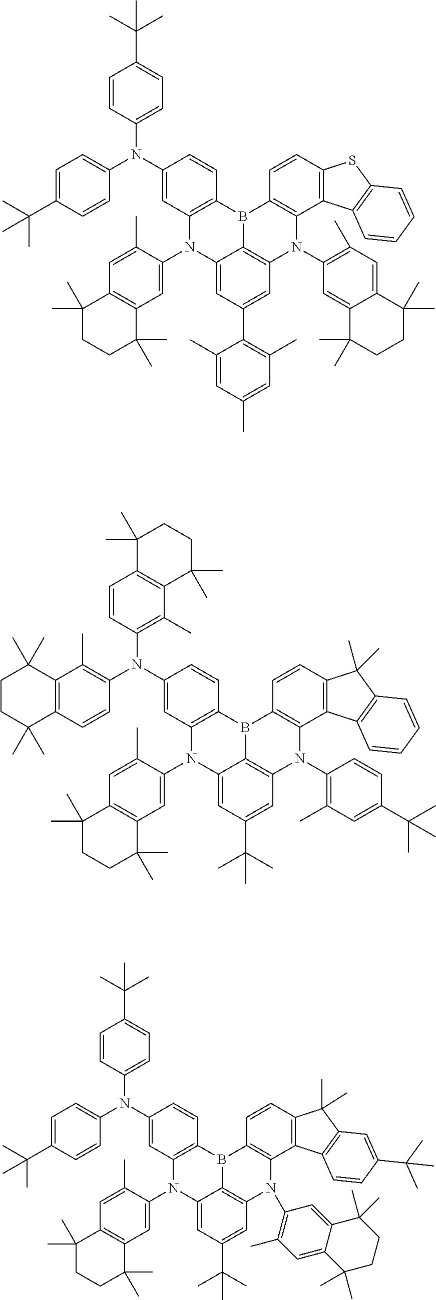

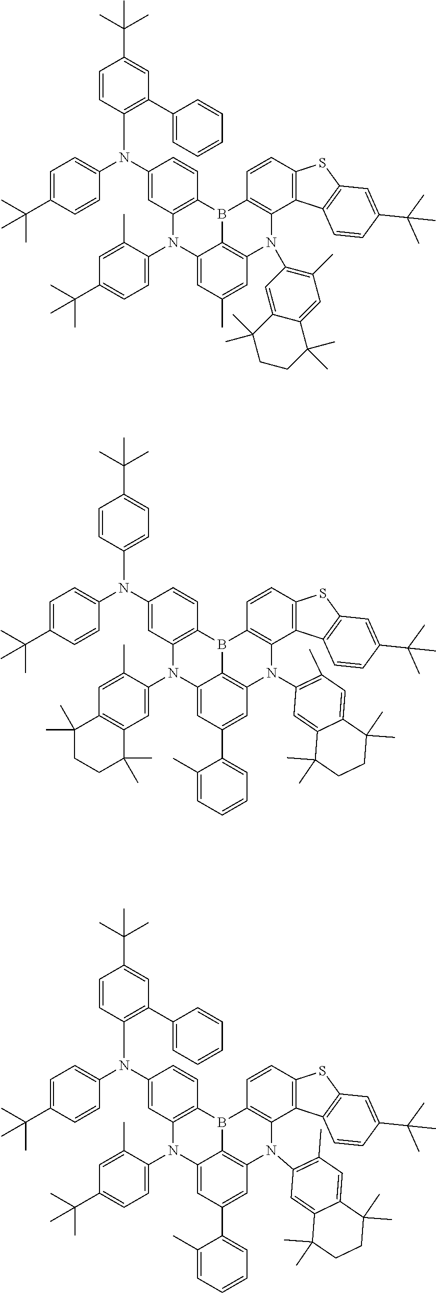

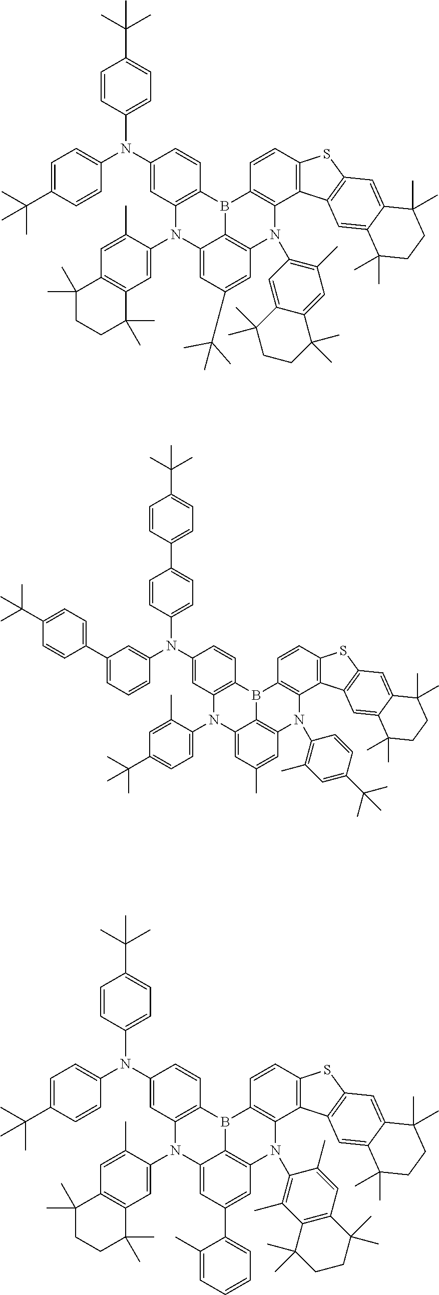

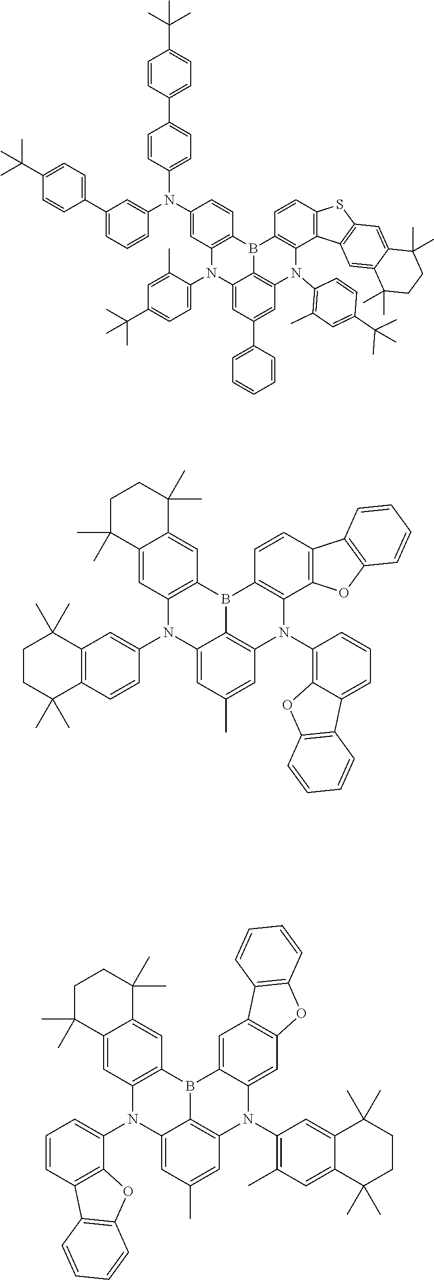

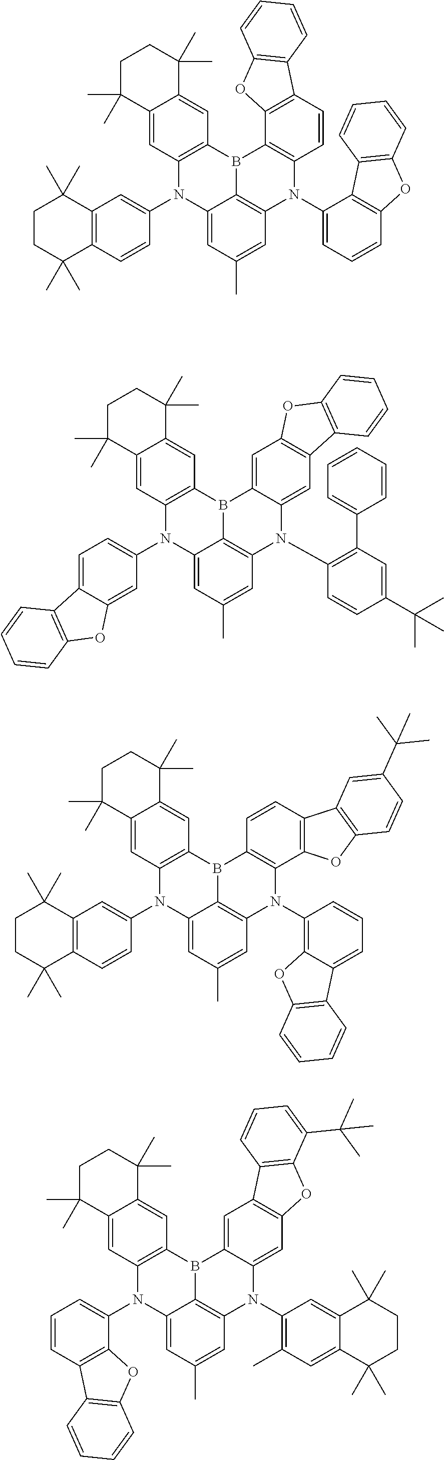

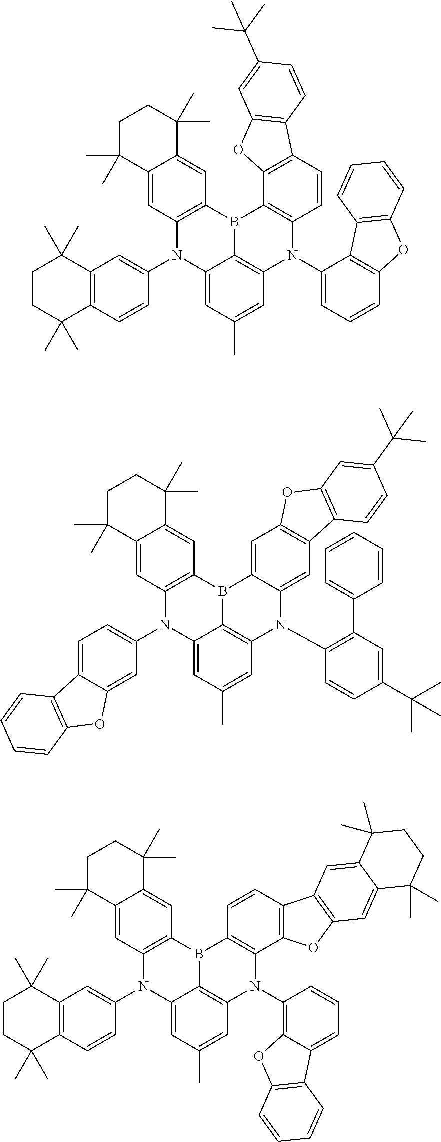 [SMILES: Cc1cc2c3c(c1)N(c1cccc4oc5ccccc5c14)c1ccc4c(oc5cc(C(C)(C)C)ccc54)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1cc(C(C)(C)C)ccc14 ; Cc1cc2c3c(c1)N(c1cccc4c1oc1ccccc14)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C]

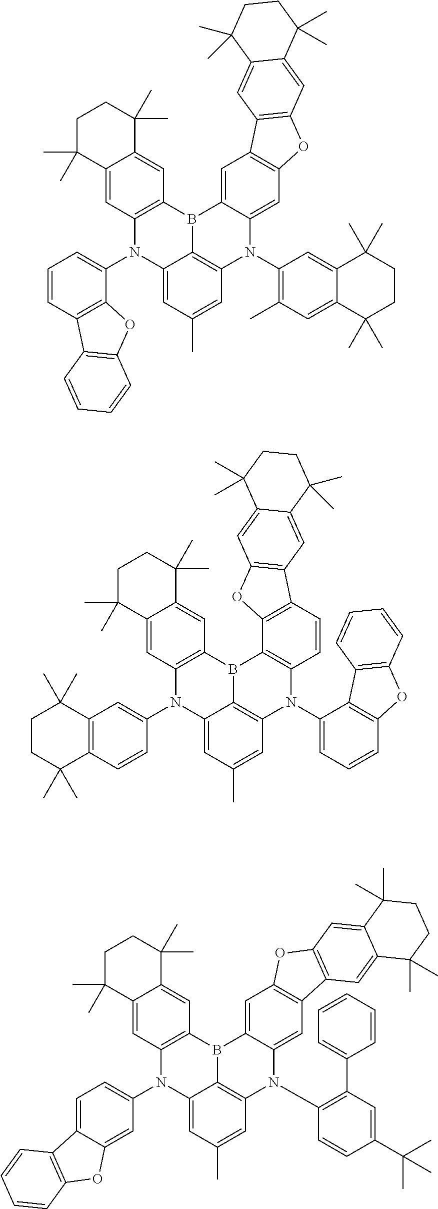 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)oc1cc2c(cc13)C(C)(C)CCC2(C)C)C(C)(C)CCC4(C)C ; Cc1cc2c3c(c1)N(c1cccc4oc5ccccc5c14)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1cc2c(cc14)C(C)(C)CCC2(C)C]

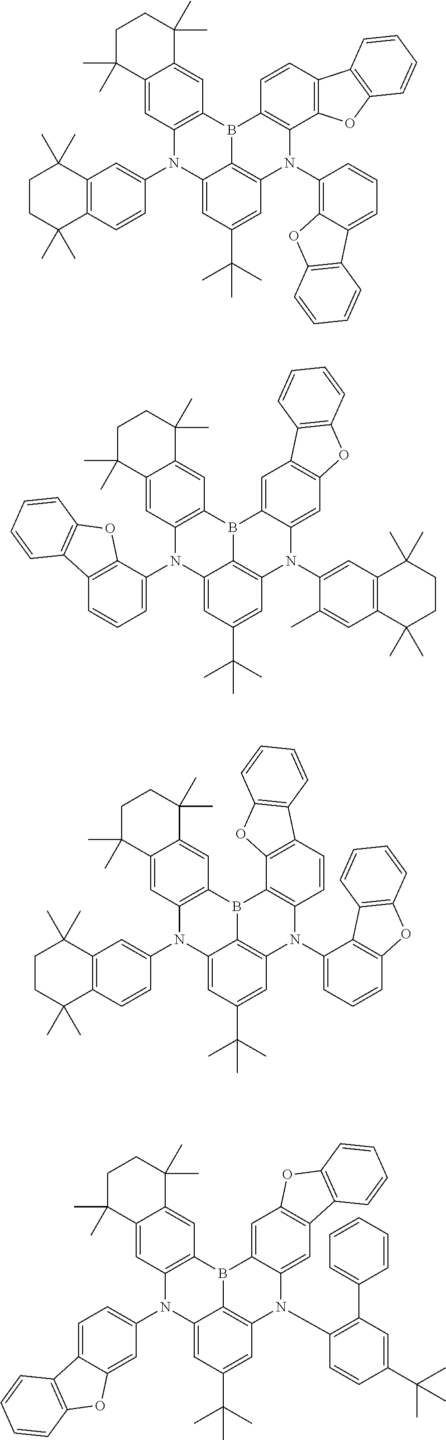

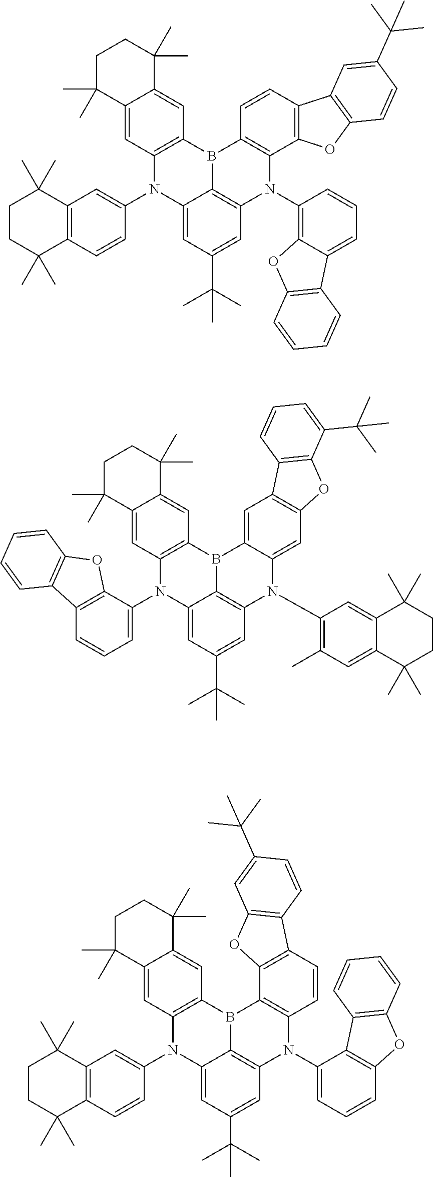 [SMILES: CC(C)(C)c1cc2c3c(c1)N(c1cccc4c1oc1ccccc14)c1c(ccc4c1oc1ccc(C(C)(C)C)cc14)B3c1cc3c(cc1N2c1ccc2c(c1)C(C)(C)CCC2(C)C)C(C)(C)CCC3(C)C ; Cc1cc2c(cc1N1c3cc4oc5c(C(C)(C)C)cccc5c4cc3B3c4cc5c(cc4N(c4cccc6c4oc4ccccc46)c4cc(C(C)(C)C)cc1c43)C(C)(C)CCC5(C)C)C(C)(C)CCC2(C)C ; CC(C)(C)c1cc2c3c(c1)N(c1cccc4oc5ccccc5c14)c1ccc4c(oc5cc(C(C)(C)C)ccc54)c1B3c1cc3c(cc1N2c1ccc2c(c1)C(C)(C)CCC2(C)C)C(C)(C)CCC3(C)C]

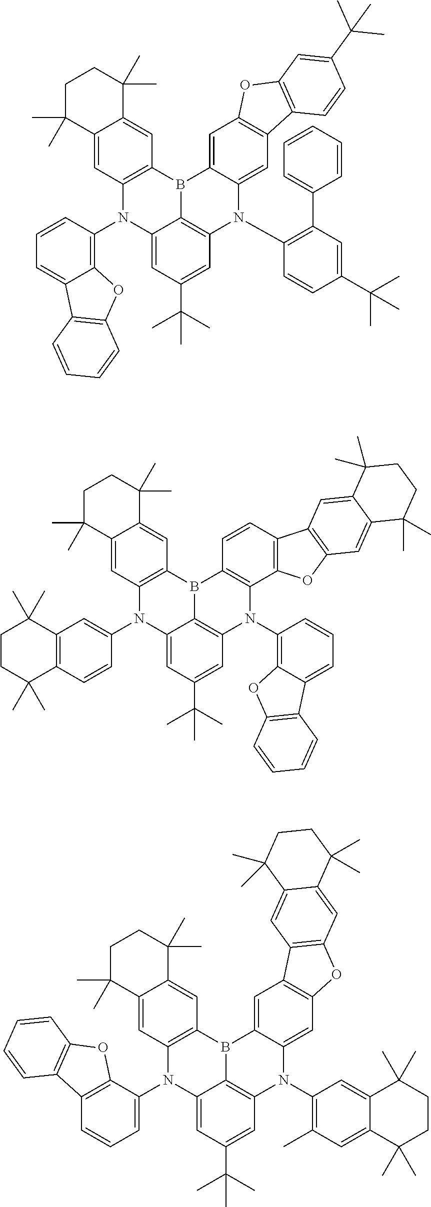 [SMILES: CC(C)(C)c1ccc(N2c3cc4c(cc3B3c5cc6c(cc5N(c5cccc7c5oc5ccccc57)c5cc(C(C)(C)C)cc2c53)C(C)(C)CCC6(C)C)oc2cc(C(C)(C)C)ccc24)c(-c2ccccc2)c1 ; CC(C)(C)c1cc2c3c(c1)N(c1cccc4c1oc1ccccc14)c1c(ccc4c1oc1cc5c(cc14)C(C)(C)CCC5(C)C)B3c1cc3c(cc1N2c1ccc2c(c1)C(C)(C)CCC2(C)C)C(C)(C)CCC3(C)C ; Cc1cc2c(cc1N1c3cc4oc5cc6c(cc5c4cc3B3c4cc5c(cc4N(c4cccc7c4oc4ccccc47)c4cc(C(C)(C)C)cc1c43)C(C)(C)CCC5(C)C)C(C)(C)CCC6(C)C)C(C)(C)CCC2(C)C]

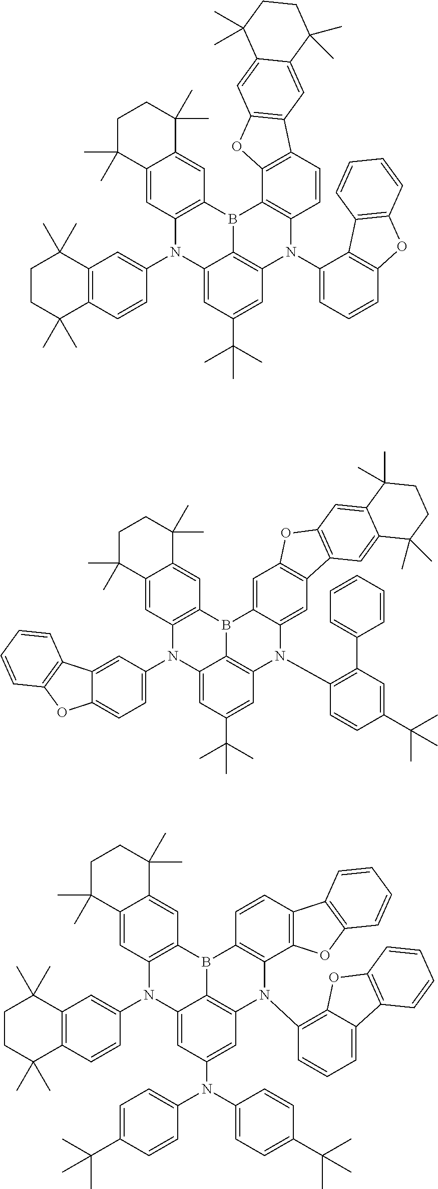 [SMILES: CC(C)(C)c1cc2c3c(c1)N(c1cccc4oc5ccccc5c14)c1ccc4c(oc5cc6c(cc54)C(C)(C)CCC6(C)C)c1B3c1cc3c(cc1N2c1ccc2c(c1)C(C)(C)CCC2(C)C)C(C)(C)CCC3(C)C ; CC(C)(C)c1ccc(N2c3cc4c(cc3B3c5cc6c(cc5N(c5ccc7oc8ccccc8c7c5)c5cc(C(C)(C)C)cc2c53)C(C)(C)CCC6(C)C)oc2cc3c(cc24)C(C)(C)CCC3(C)C)c(-c2ccccc2)c1 ; CC(C)(C)c1ccc(N(c2ccc(C(C)(C)C)cc2)c2cc3c4c(c2)N(c2cccc5c2oc2ccccc25)c2c(ccc5c2oc2ccccc25)B4c2cc4c(cc2N3c2ccc3c(c2)C(C)(C)CCC3(C)C)C(C)(C)CCC4(C)C)cc1]

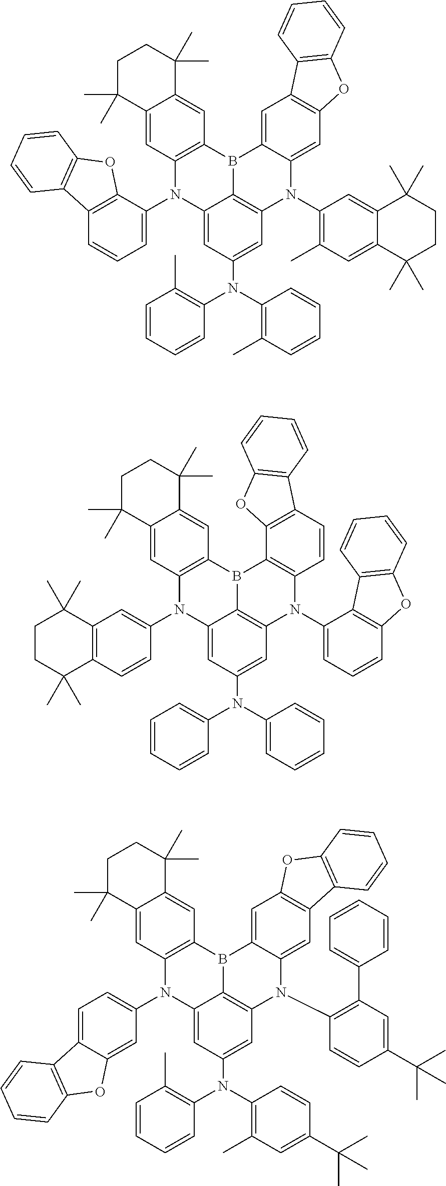 [SMILES: Cc1ccccc1N(c1cc2c3c(c1)N(c1cccc4c1oc1ccccc14)c1cc4c(cc1B3c1cc3c(cc1N2c1cc2c(cc1C)C(C)(C)CCC2(C)C)oc1ccccc13)C(C)(C)CCC4(C)C)c1ccccc1C ; CC1(C)CCC(C)(C)c2cc(N3c4cc5c(cc4B4c6c3cc(N(c3ccccc3)c3ccccc3)cc6N(c3cccc6oc7ccccc7c36)c3ccc6c(oc7ccccc76)c34)C(C)(C)CCC5(C)C)ccc21 ; Cc1ccccc1N(c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1ccccc14)c1ccc(C(C)(C)C)cc1C]

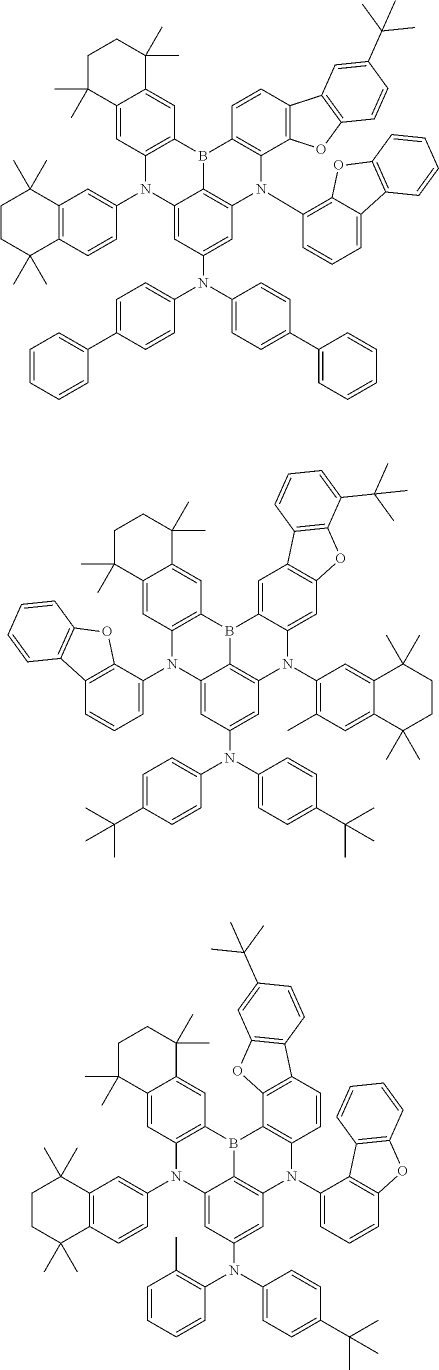 [SMILES: CC(C)(C)c1ccc2oc3c4c(ccc3c2c1)B1c2cc3c(cc2N(c2ccc5c(c2)C(C)(C)CCC5(C)C)c2cc(N(c5ccc(-c6ccccc6)cc5)c5ccc(-c6ccccc6)cc5)cc(c21)N4c1cccc2c1oc1ccccc12)C(C)(C)CCC3(C)C ; Cc1cc2c(cc1N1c3cc4oc5c(C(C)(C)C)cccc5c4cc3B3c4cc5c(cc4N(c4cccc6c4oc4ccccc46)c4cc(N(c6ccc(C(C)(C)C)cc6)c6ccc(C(C)(C)C)cc6)cc1c43)C(C)(C)CCC5(C)C)C(C)(C)CCC2(C)C ; Cc1ccccc1N(c1ccc(C(C)(C)C)cc1)c1cc2c3c(c1)N(c1cccc4oc5ccccc5c14)c1ccc4c(oc5cc(C(C)(C)C)ccc54)c1B3c1cc3c(cc1N2c1ccc2c(c1)C(C)(C)CCC2(C)C)C(C)(C)CCC3(C)C]

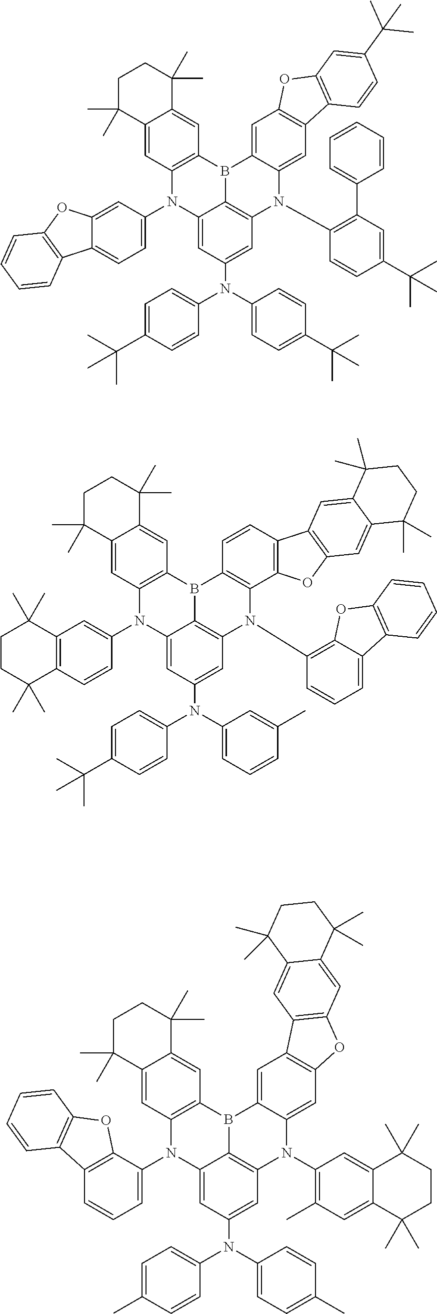 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)oc2ccccc23)C(C)(C)CCC4(C)C)oc2cc(C(C)(C)C)ccc25)cc1 ; Cc1cccc(N(c2ccc(C(C)(C)C)cc2)c2cc3c4c(c2)N(c2cccc5c2oc2ccccc25)c2c(ccc5c2oc2cc6c(cc25)C(C)(C)CCC6(C)C)B4c2cc4c(cc2N3c2ccc3c(c2)C(C)(C)CCC3(C)C)C(C)(C)CCC4(C)C)c1 ; Cc1ccc(N(c2ccc(C)cc2)c2cc3c4c(c2)N(c2cccc5c2oc2ccccc25)c2cc5c(cc2B4c2cc4c(cc2N3c2cc3c(cc2C)C(C)(C)CCC3(C)C)oc2cc3c(cc24)C(C)(C)CCC3(C)C)C(C)(C)CCC5(C)C)cc1]

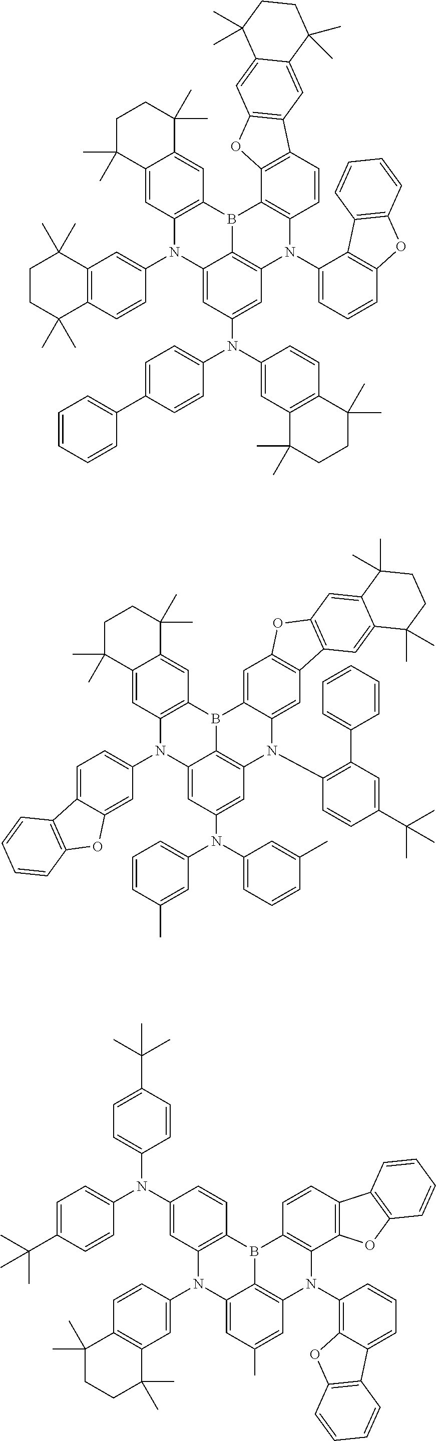

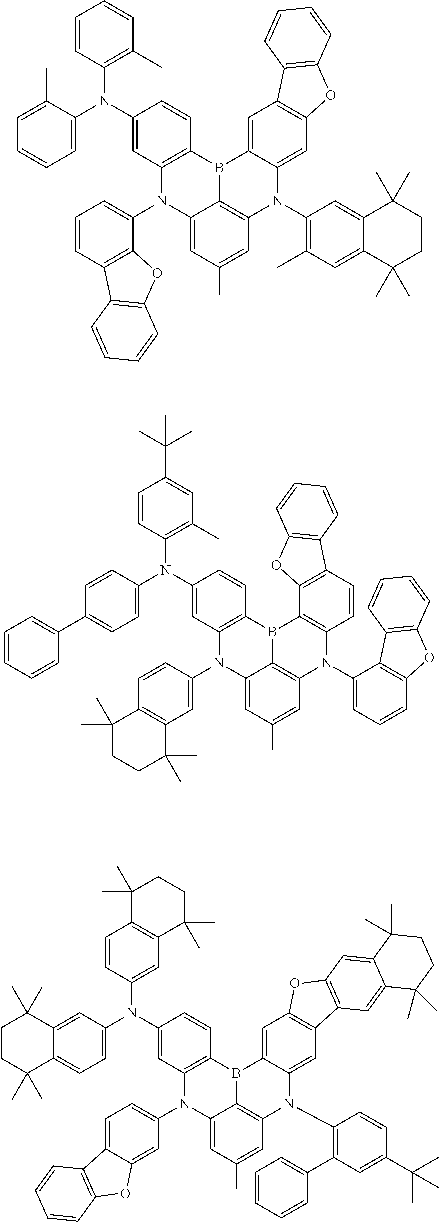 [SMILES: Cc1cc2c3c(c1)N(c1cccc4c1oc1ccccc14)c1cc(N(c4ccccc4C)c4ccccc4C)ccc1B3c1cc3c(cc1N2c1cc2c(cc1C)C(C)(C)CCC2(C)C)oc1ccccc13 ; Cc1cc2c3c(c1)N(c1cccc4oc5ccccc5c14)c1ccc4c(oc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)oc1cc2c(cc14)C(C)(C)CCC2(C)C]

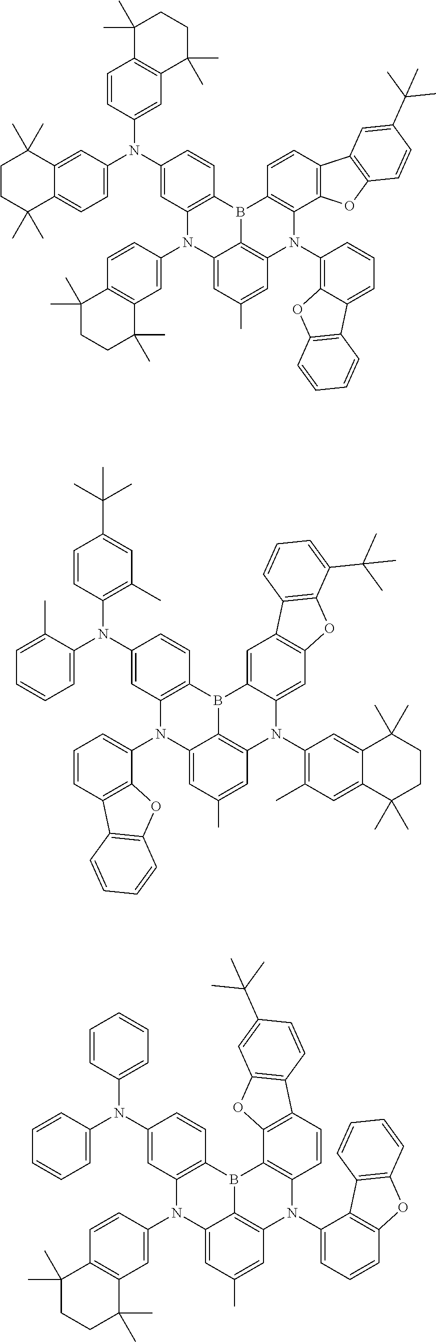

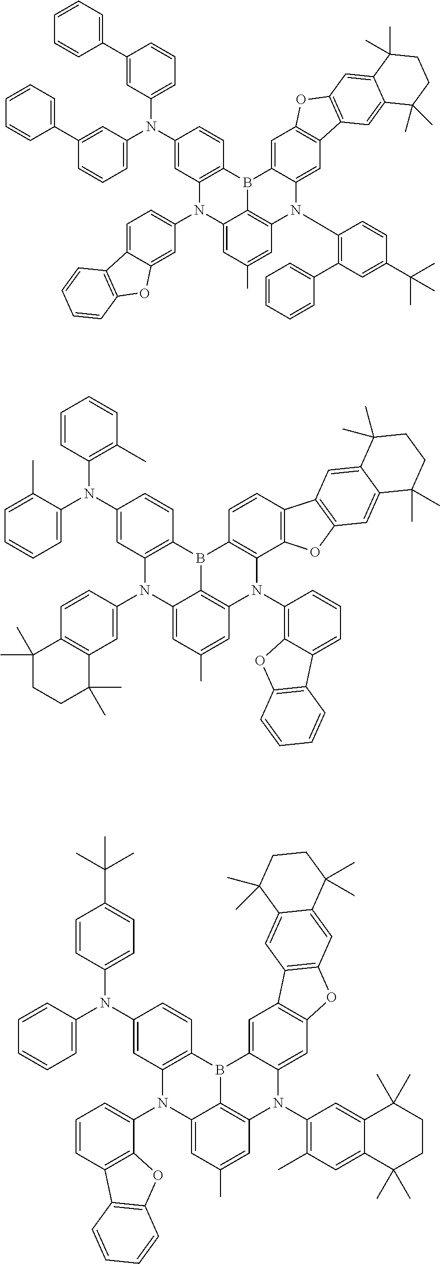

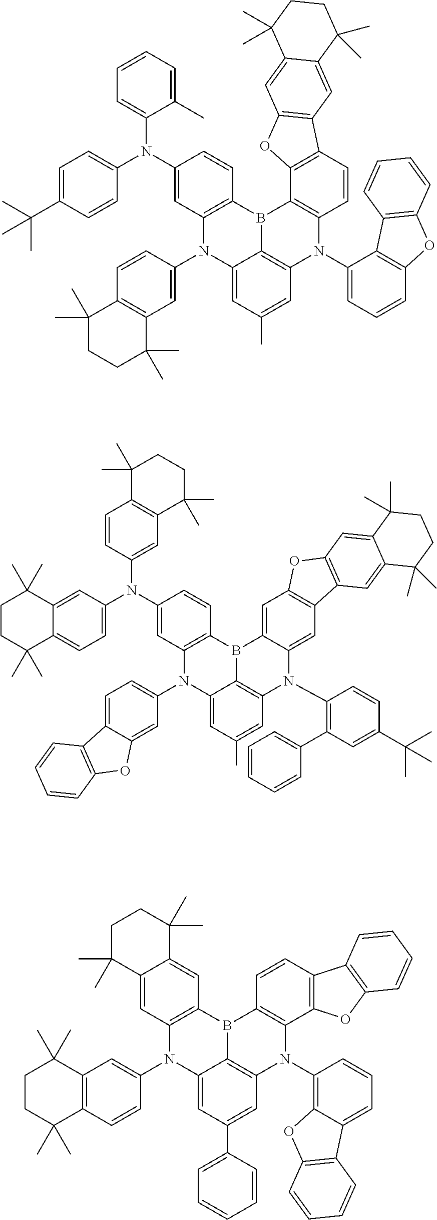 [SMILES: Cc1cc2c3c(c1)N(c1cccc4oc5ccccc5c14)c1ccc4c(oc5cc6c(cc54)C(C)(C)CCC6(C)C)c1B3c1ccc(N(c3ccc(C(C)(C)C)cc3)c3ccccc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)oc1cc2c(cc14)C(C)(C)CCC2(C)C ; CC1(C)CCC(C)(C)c2cc(N3c4cc5c(cc4B4c6ccc7c(oc8ccccc87)c6N(c6cccc7c6oc6ccccc67)c6cc(-c7ccccc7)cc3c64)C(C)(C)CCC5(C)C)ccc21]

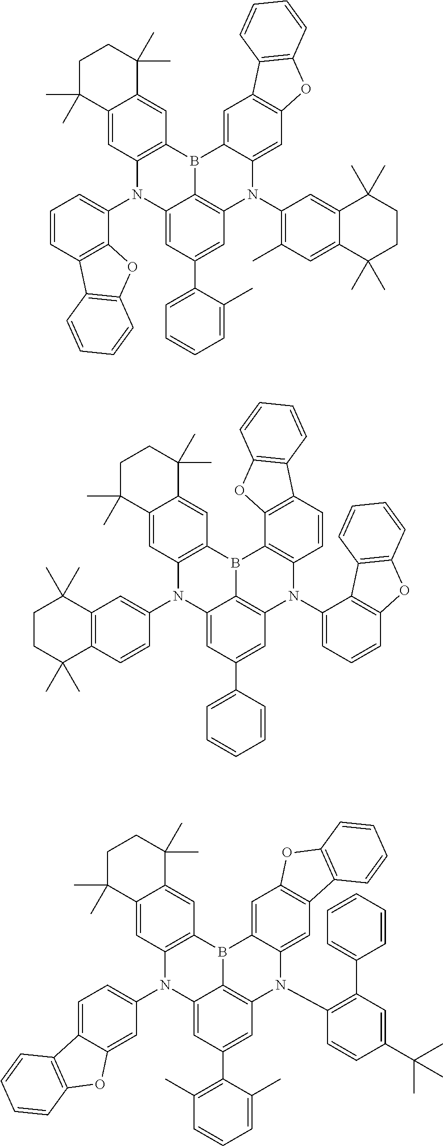 [SMILES: Cc1ccccc1-c1cc2c3c(c1)N(c1cccc4c1oc1ccccc14)c1cc4c(cc1B3c1cc3c(cc1N2c1cc2c(cc1C)C(C)(C)CCC2(C)C)oc1ccccc13)C(C)(C)CCC4(C)C ; CC1(C)CCC(C)(C)c2cc(N3c4cc5c(cc4B4c6c3cc(-c3ccccc3)cc6N(c3cccc6oc7ccccc7c36)c3ccc6c(oc7ccccc76)c34)C(C)(C)CCC5(C)C)ccc21 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1ccccc14]

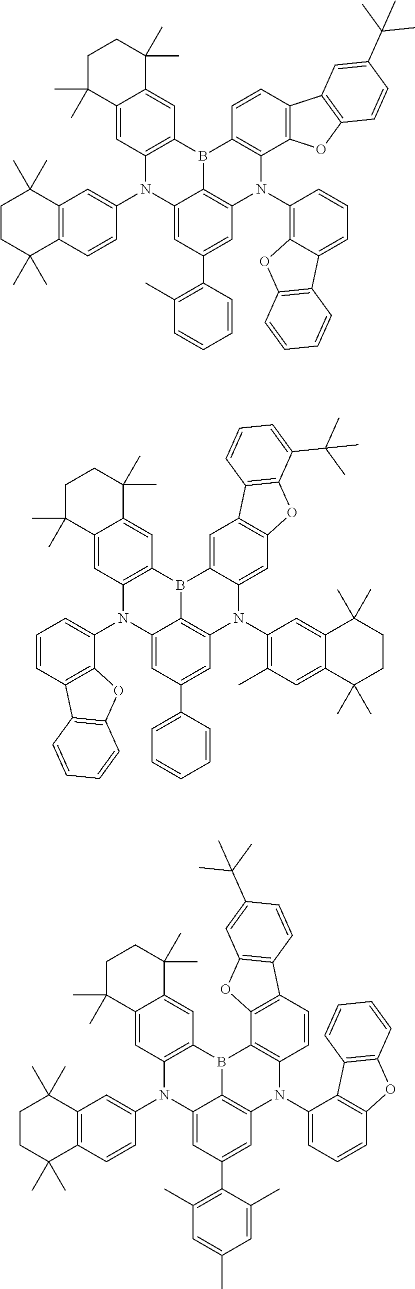

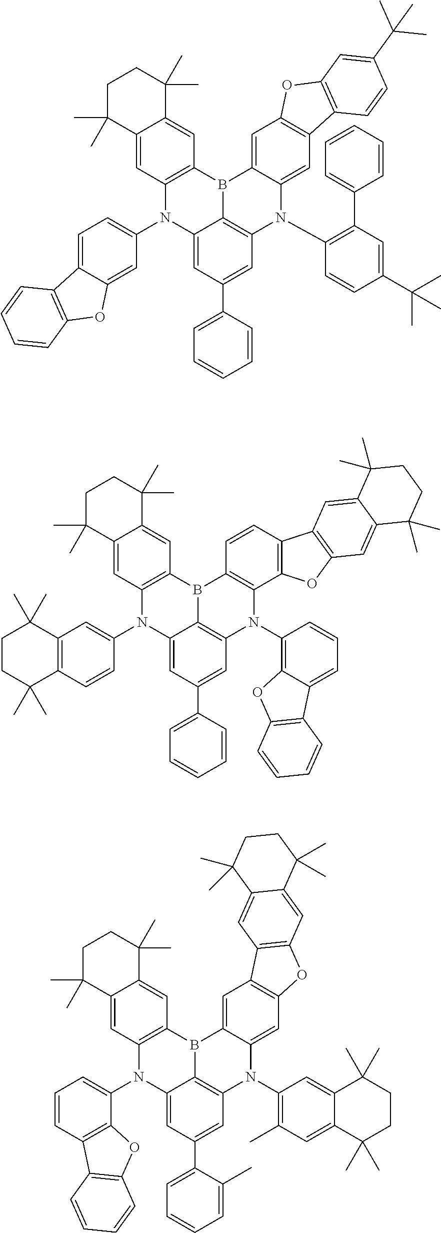

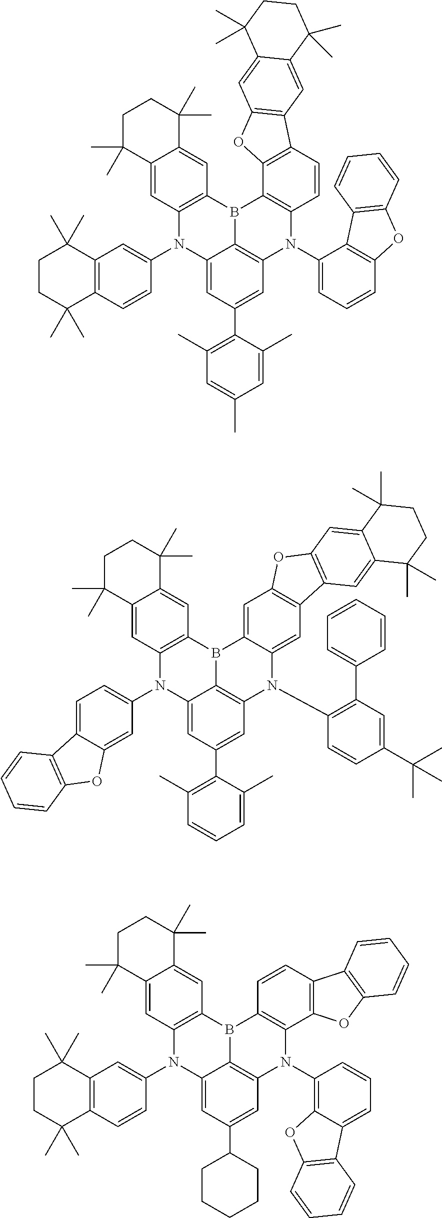 [SMILES: Cc1cc(C)c(-c2cc3c4c(c2)N(c2cccc5oc6ccccc6c25)c2ccc5c(oc6cc7c(cc65)C(C)(C)CCC7(C)C)c2B4c2cc4c(cc2N3c2ccc3c(c2)C(C)(C)CCC3(C)C)C(C)(C)CCC4(C)C)c(C)c1 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)oc1cc2c(cc14)C(C)(C)CCC2(C)C ; CC1(C)CCC(C)(C)c2cc(N3c4cc5c(cc4B4c6ccc7c(oc8ccccc87)c6N(c6cccc7c6oc6ccccc67)c6cc(C7CCCCC7)cc3c64)C(C)(C)CCC5(C)C)ccc21]

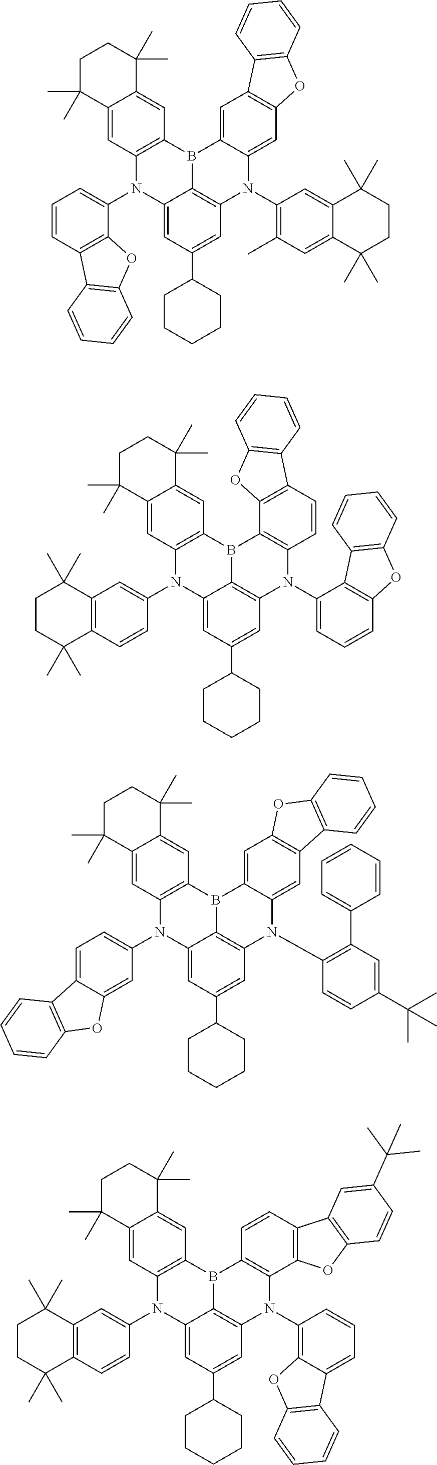 [SMILES: Cc1cc2c(cc1N1c3cc4oc5ccccc5c4cc3B3c4cc5c(cc4N(c4cccc6c4oc4ccccc46)c4cc(C6CCCCC6)cc1c43)C(C)(C)CCC5(C)C)C(C)(C)CCC2(C)C ; CC1(C)CCC(C)(C)c2cc(N3c4cc5c(cc4B4c6c3cc(C3CCCCC3)cc6N(c3cccc6oc7ccccc7c36)c3ccc6c(oc7ccccc76)c34)C(C)(C)CCC5(C)C)ccc21 ; CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)oc2ccccc24)c(-c2ccccc2)c1 ; CC(C)(C)c1ccc2oc3c4c(ccc3c2c1)B1c2cc3c(cc2N(c2ccc5c(c2)C(C)(C)CCC5(C)C)c2cc(C5CCCCC5)cc(c21)N4c1cccc2c1oc1ccccc12)C(C)(C)CCC3(C)C]

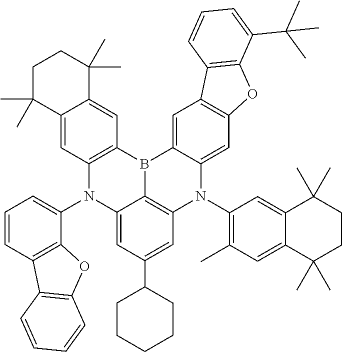 [SMILES: Cc1cc2c(cc1N1c3cc4oc5c(C(C)(C)C)cccc5c4cc3B3c4cc5c(cc4N(c4cccc6c4oc4ccccc46)c4cc(C6CCCCC6)cc1c43)C(C)(C)CCC5(C)C)C(C)(C)CCC2(C)C]

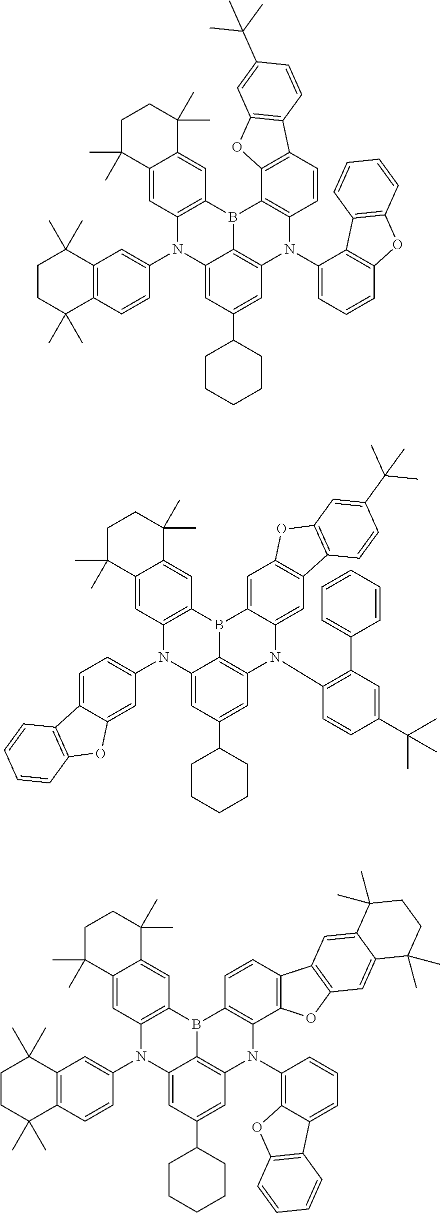 [SMILES: CC(C)(C)c1ccc2c(c1)oc1c3c(ccc12)N(c1cccc2oc4ccccc4c12)c1cc(C2CCCCC2)cc2c1B3c1cc3c(cc1N2c1ccc2c(c1)C(C)(C)CCC2(C)C)C(C)(C)CCC3(C)C ; CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)oc2cc(C(C)(C)C)ccc24)c(-c2ccccc2)c1 ; CC1(C)CCC(C)(C)c2cc(N3c4cc5c(cc4B4c6ccc7c(oc8cc9c(cc87)C(C)(C)CCC9(C)C)c6N(c6cccc7c6oc6ccccc67)c6cc(C7CCCCC7)cc3c64)C(C)(C)CCC5(C)C)ccc21]

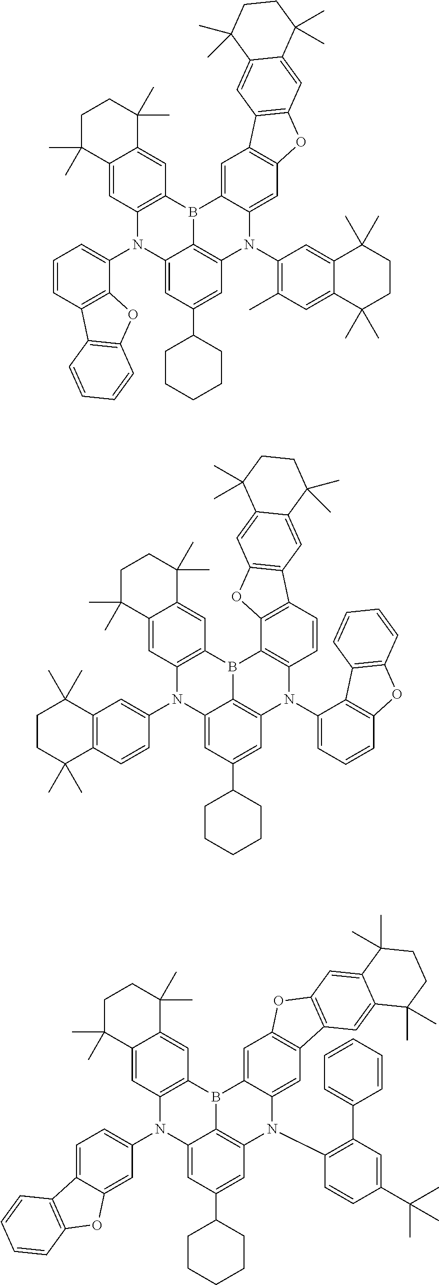 [SMILES: Cc1cc2c(cc1N1c3cc4oc5cc6c(cc5c4cc3B3c4cc5c(cc4N(c4cccc7c4oc4ccccc47)c4cc(C7CCCCC7)cc1c43)C(C)(C)CCC5(C)C)C(C)(C)CCC6(C)C)C(C)(C)CCC2(C)C ; CC1(C)CCC(C)(C)c2cc(N3c4cc5c(cc4B4c6c3cc(C3CCCCC3)cc6N(c3cccc6oc7ccccc7c36)c3ccc6c(oc7cc8c(cc76)C(C)(C)CCC8(C)C)c34)C(C)(C)CCC5(C)C)ccc21 ; CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)oc2cc3c(cc24)C(C)(C)CCC3(C)C)c(-c2ccccc2)c1]

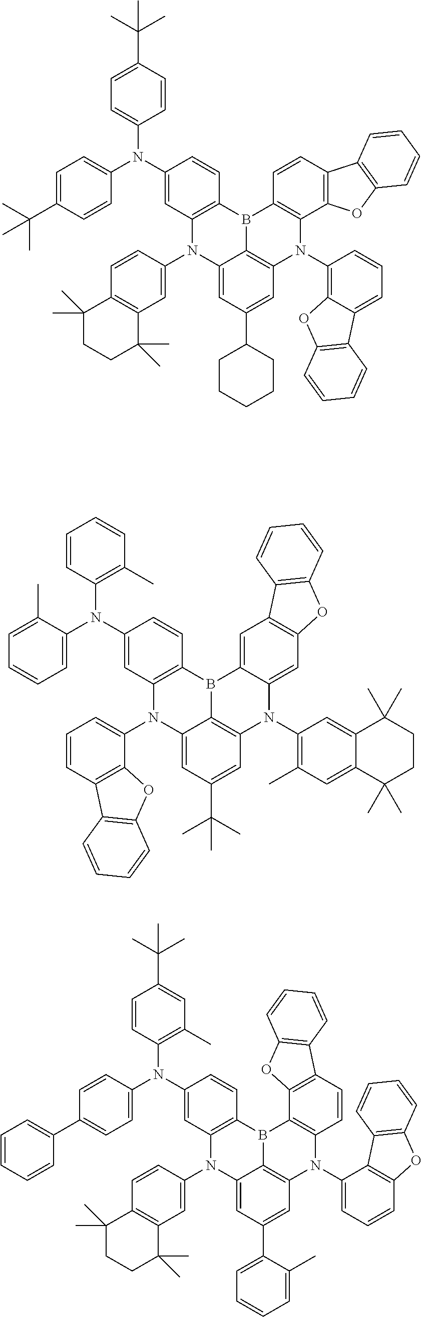 [SMILES: CC(C)(C)c1ccc(N(c2ccc(C(C)(C)C)cc2)c2ccc3c(c2)N(c2ccc4c(c2)C(C)(C)CCC4(C)C)c2cc(C4CCCCC4)cc4c2B3c2ccc3c(oc5ccccc53)c2N4c2cccc3c2oc2ccccc23)cc1 ; Cc1ccccc1N(c1ccc2c(c1)N(c1cccc3c1oc1ccccc13)c1cc(C(C)(C)C)cc3c1B2c1cc2c(cc1N3c1cc3c(cc1C)C(C)(C)CCC3(C)C)oc1ccccc12)c1ccccc1C ; Cc1ccccc1-c1cc2c3c(c1)N(c1cccc4oc5ccccc5c14)c1ccc4c(oc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C]

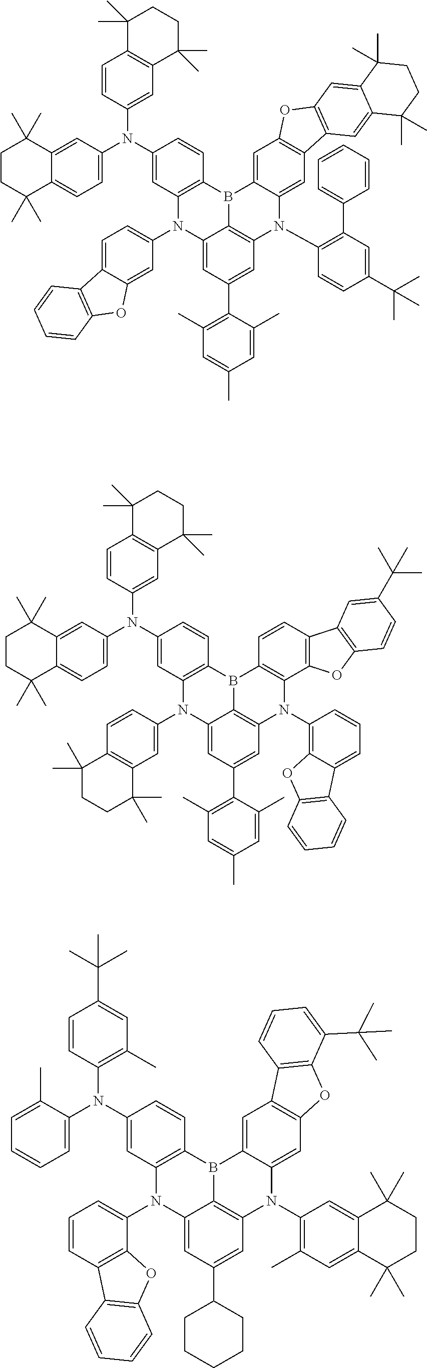

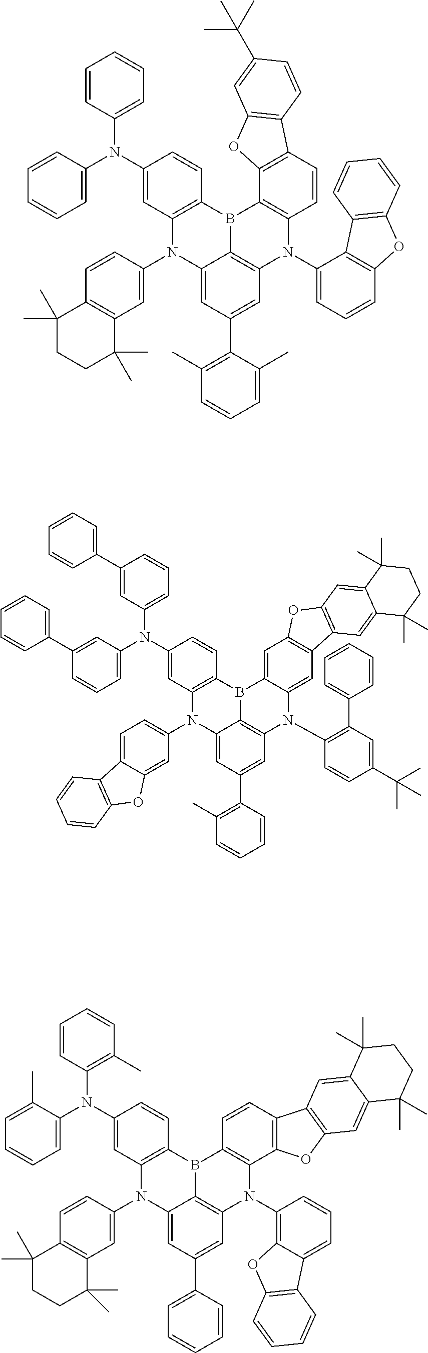

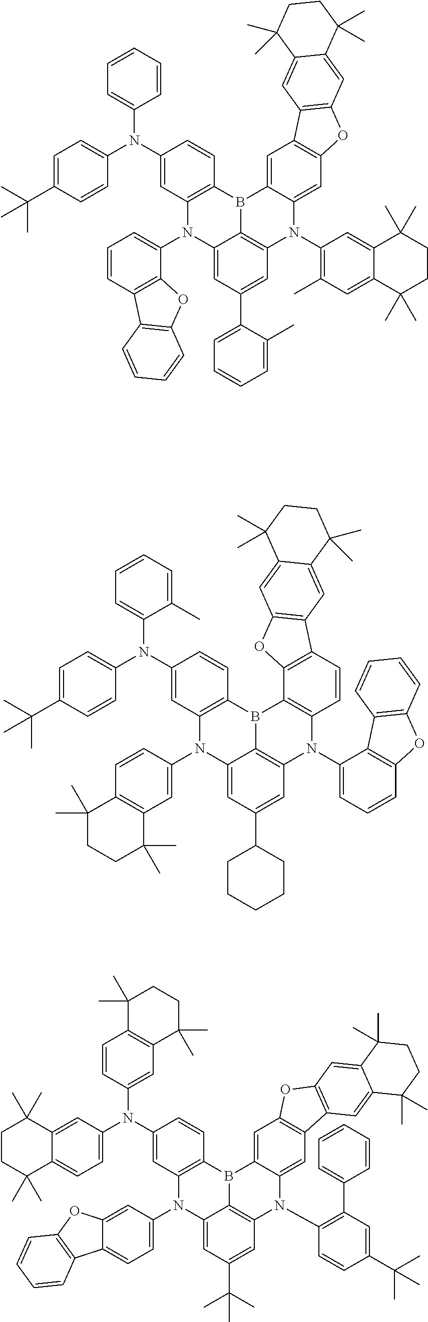 [SMILES: Cc1ccccc1-c1cc2c3c(c1)N(c1cccc4c1oc1ccccc14)c1cc(N(c4ccccc4)c4ccc(C(C)(C)C)cc4)ccc1B3c1cc3c(cc1N2c1cc2c(cc1C)C(C)(C)CCC2(C)C)oc1cc2c(cc13)C(C)(C)CCC2(C)C ; Cc1ccccc1N(c1ccc(C(C)(C)C)cc1)c1ccc2c(c1)N(c1ccc3c(c1)C(C)(C)CCC3(C)C)c1cc(C3CCCCC3)cc3c1B2c1c(ccc2c1oc1cc4c(cc12)C(C)(C)CCC4(C)C)N3c1cccc2oc3ccccc3c12 ; CC(C)(C)c1ccc(N2c3cc4c(cc3B3c5ccc(N(c6ccc7c(c6)C(C)(C)CCC7(C)C)c6ccc7c(c6)C(C)(C)CCC7(C)C)cc5N(c5ccc6c(c5)oc5ccccc56)c5cc(C(C)(C)C)cc2c53)oc2cc3c(cc24)C(C)(C)CCC3(C)C)c(-c2ccccc2)c1]

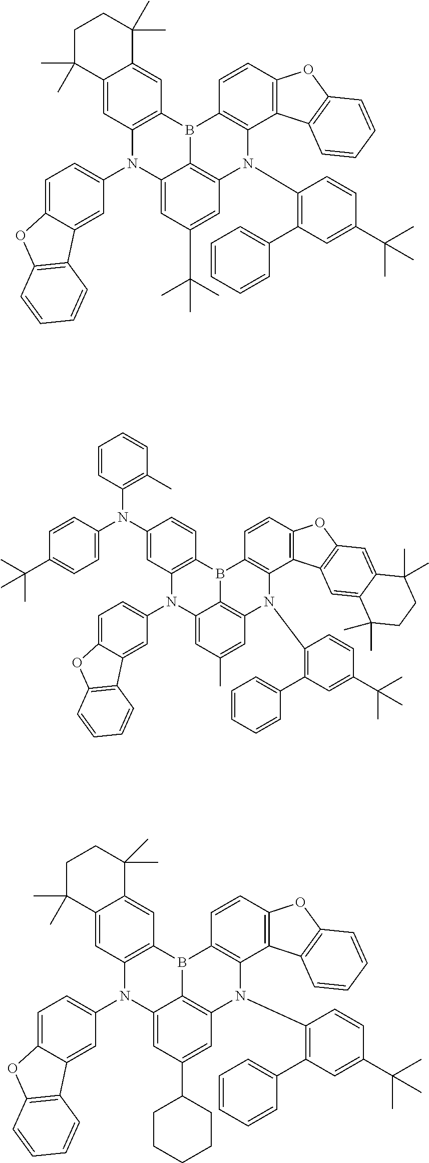

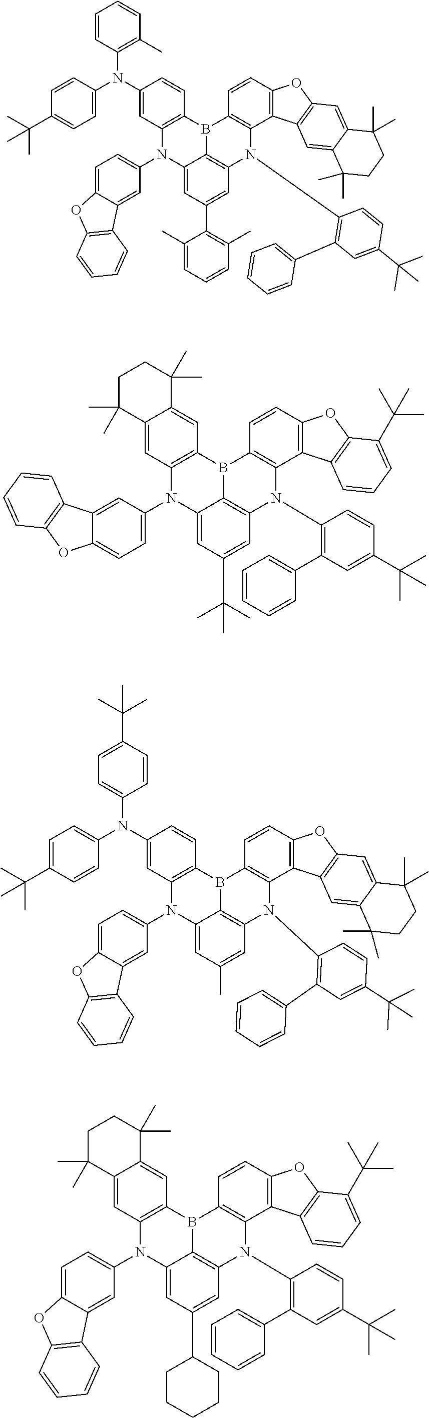

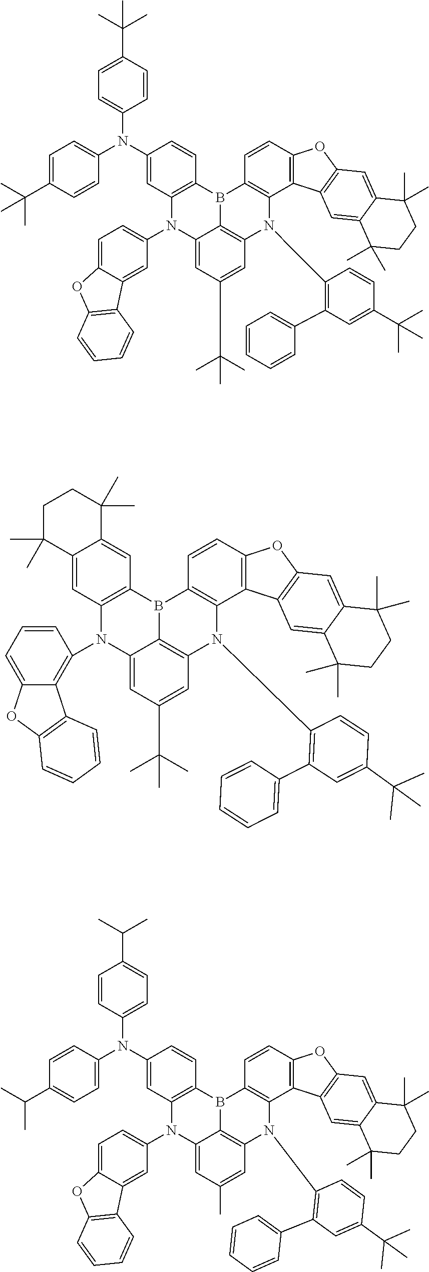

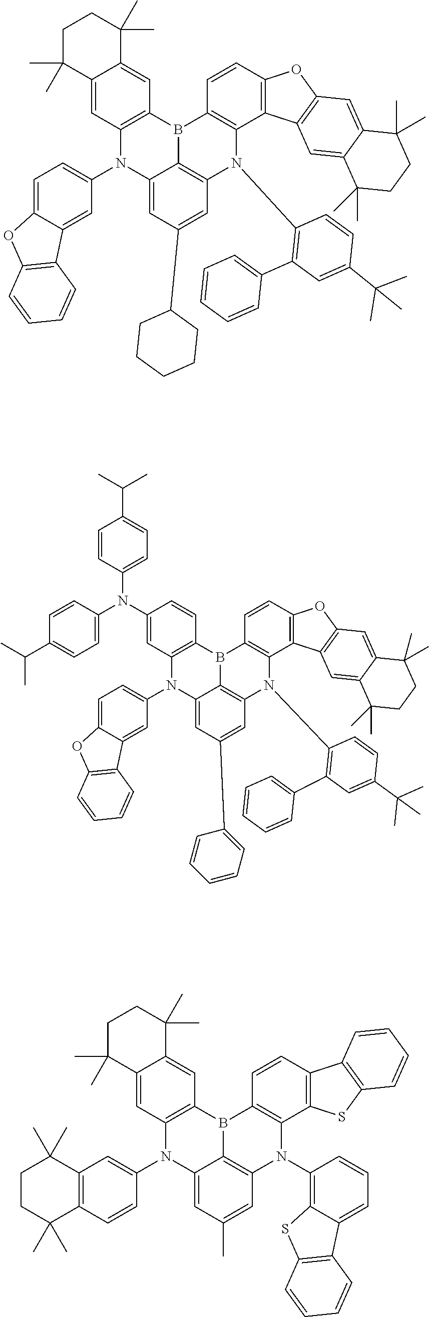

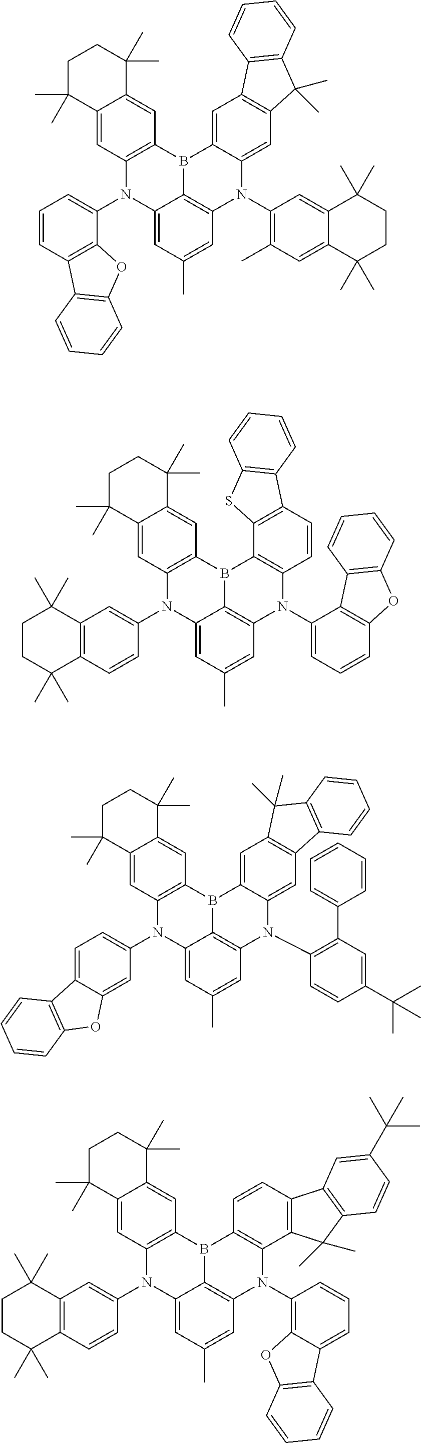 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)C(C)(C)c1ccccc1-3)C(C)(C)CCC4(C)C ; Cc1cc2c3c(c1)N(c1cccc4oc5ccccc5c14)c1ccc4c(sc5ccccc54)c1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)C(C)(C)c1ccccc1-4 ; Cc1cc2c3c(c1)N(c1cccc4c1oc1ccccc14)c1c(ccc4c1C(C)(C)c1ccc(C(C)(C)C)cc1-4)B3c1cc3c(cc1N2c1ccc2c(c1)C(C)(C)CCC2(C)C)C(C)(C)CCC3(C)C]

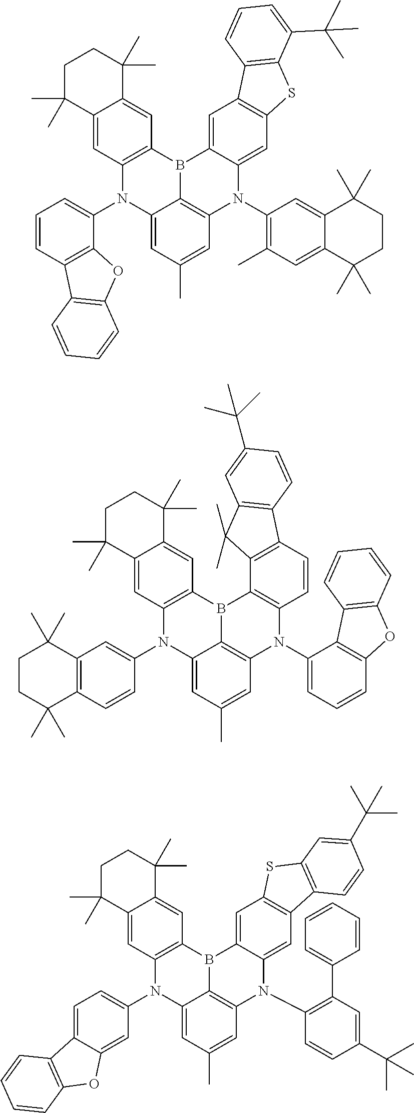 [SMILES: Cc1cc2c3c(c1)N(c1cccc4c1oc1ccccc14)c1cc4c(cc1B3c1cc3c(cc1N2c1cc2c(cc1C)C(C)(C)CCC2(C)C)sc1c(C(C)(C)C)cccc13)C(C)(C)CCC4(C)C ; Cc1cc2c3c(c1)N(c1cccc4oc5ccccc5c14)c1ccc4c(c1B3c1cc3c(cc1N2c1ccc2c(c1)C(C)(C)CCC2(C)C)C(C)(C)CCC3(C)C)C(C)(C)c1cc(C(C)(C)C)ccc1-4 ; Cc1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)sc1cc(C(C)(C)C)ccc14]

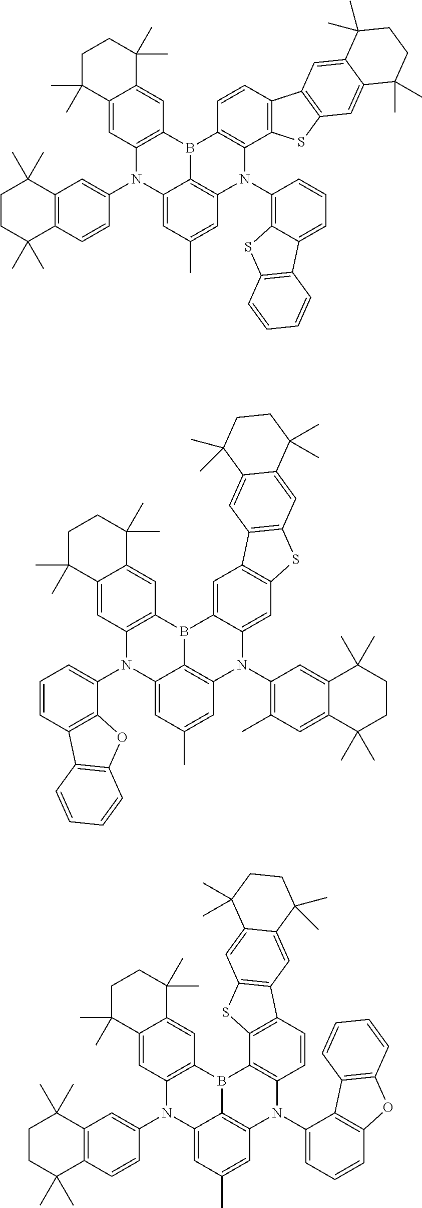

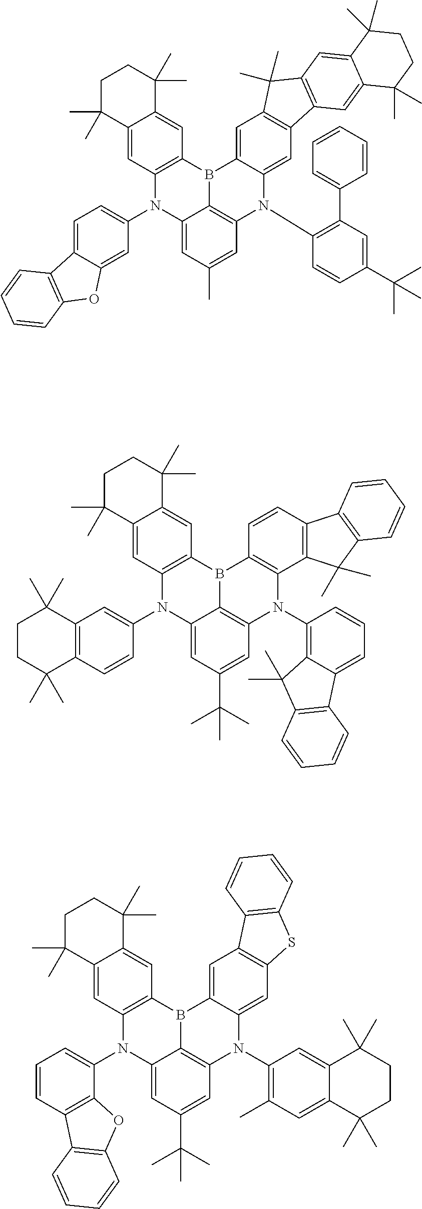

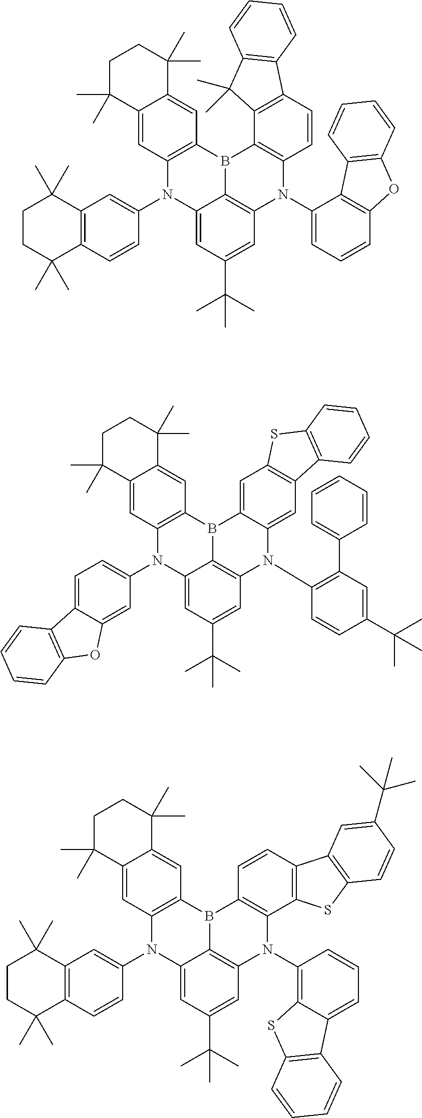 [SMILES: CC(C)(C)c1cc2c3c(c1)N(c1cccc4oc5ccccc5c14)c1ccc4c(c1B3c1cc3c(cc1N2c1ccc2c(c1)C(C)(C)CCC2(C)C)C(C)(C)CCC3(C)C)C(C)(C)c1ccccc1-4 ; CC(C)(C)c1ccc(N2c3cc4c(cc3B3c5cc6c(cc5N(c5ccc7c(c5)oc5ccccc57)c5cc(C(C)(C)C)cc2c53)C(C)(C)CCC6(C)C)sc2ccccc24)c(-c2ccccc2)c1 ; CC(C)(C)c1cc2c3c(c1)N(c1cccc4c1sc1ccccc14)c1c(ccc4c1sc1ccc(C(C)(C)C)cc14)B3c1cc3c(cc1N2c1ccc2c(c1)C(C)(C)CCC2(C)C)C(C)(C)CCC3(C)C]

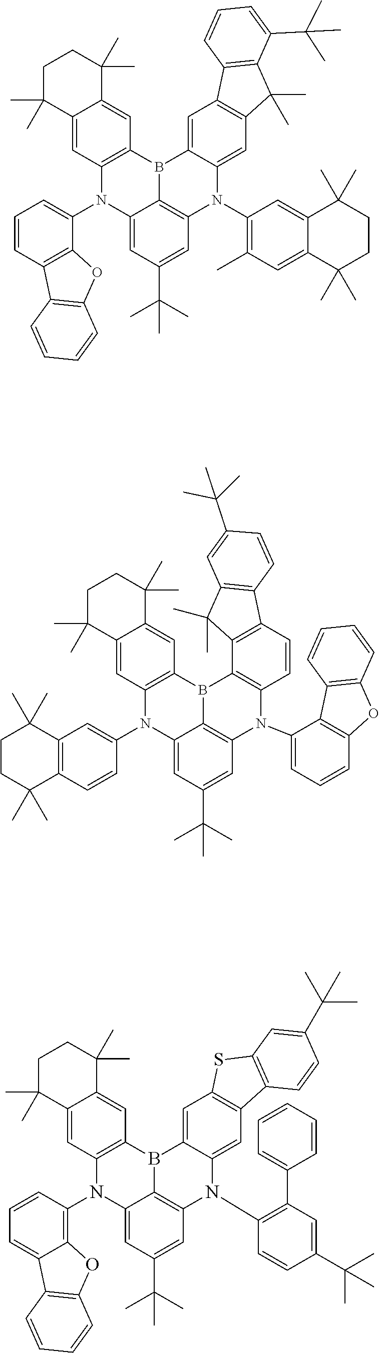 [SMILES: Cc1cc2c(cc1N1c3cc4c(cc3B3c5cc6c(cc5N(c5cccc7c5oc5ccccc57)c5cc(C(C)(C)C)cc1c53)C(C)(C)CCC6(C)C)-c1cccc(C(C)(C)C)c1C4(C)C)C(C)(C)CCC2(C)C ; CC(C)(C)c1cc2c3c(c1)N(c1cccc4oc5ccccc5c14)c1ccc4c(c1B3c1cc3c(cc1N2c1ccc2c(c1)C(C)(C)CCC2(C)C)C(C)(C)CCC3(C)C)C(C)(C)c1cc(C(C)(C)C)ccc1-4 ; CC(C)(C)c1ccc(N2c3cc4c(cc3B3c5cc6c(cc5N(c5cccc7c5oc5ccccc57)c5cc(C(C)(C)C)cc2c53)C(C)(C)CCC6(C)C)sc2cc(C(C)(C)C)ccc24)c(-c2ccccc2)c1]

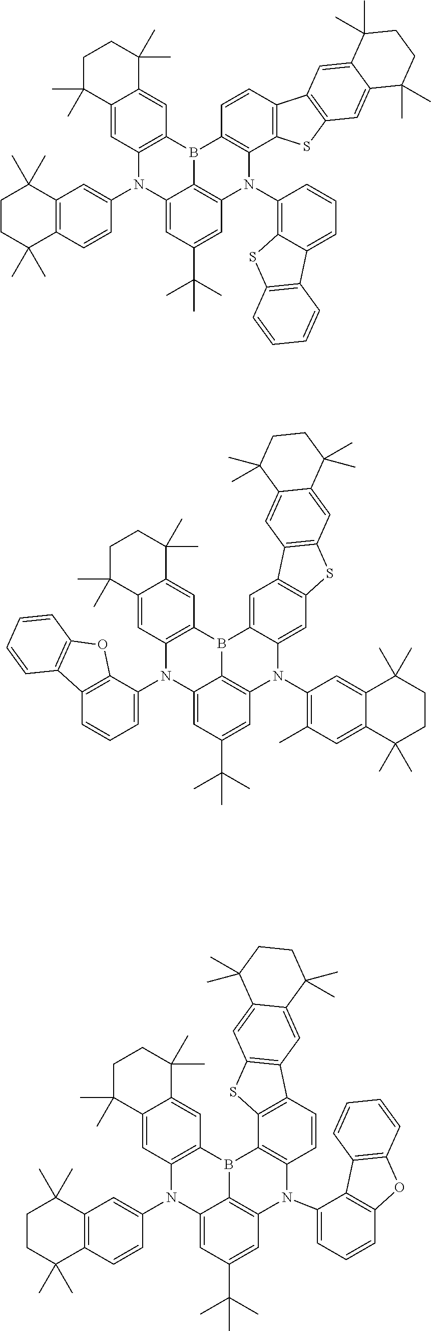 [SMILES: CC(C)(C)c1cc2c3c(c1)N(c1cccc4c1sc1ccccc14)c1c(ccc4c1sc1cc5c(cc14)C(C)(C)CCC5(C)C)B3c1cc3c(cc1N2c1ccc2c(c1)C(C)(C)CCC2(C)C)C(C)(C)CCC3(C)C ; Cc1cc2c(cc1N1c3cc4sc5cc6c(cc5c4cc3B3c4cc5c(cc4N(c4cccc7c4oc4ccccc47)c4cc(C(C)(C)C)cc1c43)C(C)(C)CCC5(C)C)C(C)(C)CCC6(C)C)C(C)(C)CCC2(C)C ; CC(C)(C)c1cc2c3c(c1)N(c1cccc4oc5ccccc5c14)c1ccc4c(sc5cc6c(cc54)C(C)(C)CCC6(C)C)c1B3c1cc3c(cc1N2c1ccc2c(c1)C(C)(C)CCC2(C)C)C(C)(C)CCC3(C)C]

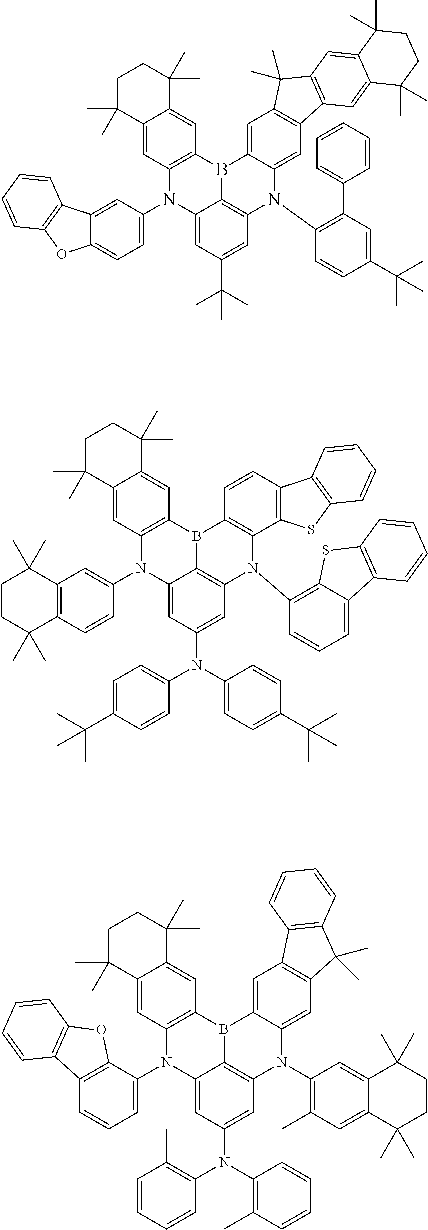 [SMILES: CC(C)(C)c1ccc(N2c3cc4c(cc3B3c5cc6c(cc5N(c5ccc7oc8ccccc8c7c5)c5cc(C(C)(C)C)cc2c53)C(C)(C)CCC6(C)C)C(C)(C)c2cc3c(cc2-4)C(C)(C)CCC3(C)C)c(-c2ccccc2)c1 ; CC(C)(C)c1ccc(N(c2ccc(C(C)(C)C)cc2)c2cc3c4c(c2)N(c2cccc5c2sc2ccccc25)c2c(ccc5c2sc2ccccc25)B4c2cc4c(cc2N3c2ccc3c(c2)C(C)(C)CCC3(C)C)C(C)(C)CCC4(C)C)cc1 ; Cc1ccccc1N(c1cc2c3c(c1)N(c1cccc4c1oc1ccccc14)c1cc4c(cc1B3c1cc3c(cc1N2c1cc2c(cc1C)C(C)(C)CCC2(C)C)C(C)(C)c1ccccc1-3)C(C)(C)CCC4(C)C)c1ccccc1C]

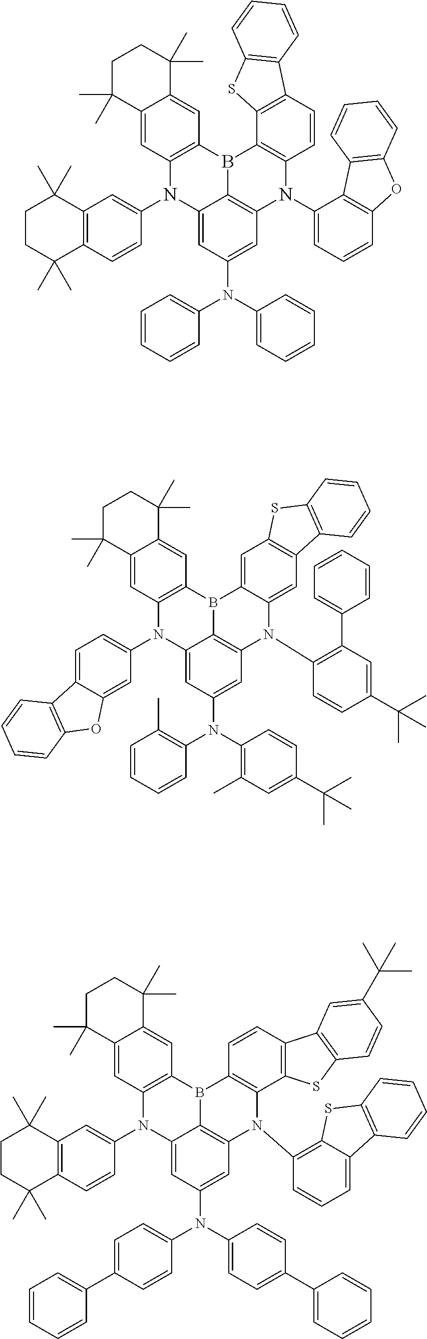 [SMILES: CC1(C)CCC(C)(C)c2cc(N3c4cc5c(cc4B4c6c3cc(N(c3ccccc3)c3ccccc3)cc6N(c3cccc6oc7ccccc7c36)c3ccc6c(sc7ccccc76)c34)C(C)(C)CCC5(C)C)ccc21 ; Cc1ccccc1N(c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)sc1ccccc14)c1ccc(C(C)(C)C)cc1C ; CC(C)(C)c1ccc2sc3c4c(ccc3c2c1)B1c2cc3c(cc2N(c2ccc5c(c2)C(C)(C)CCC5(C)C)c2cc(N(c5ccc(-c6ccccc6)cc5)c5ccc(-c6ccccc6)cc5)cc(c21)N4c1cccc2c1sc1ccccc12)C(C)(C)CCC3(C)C]

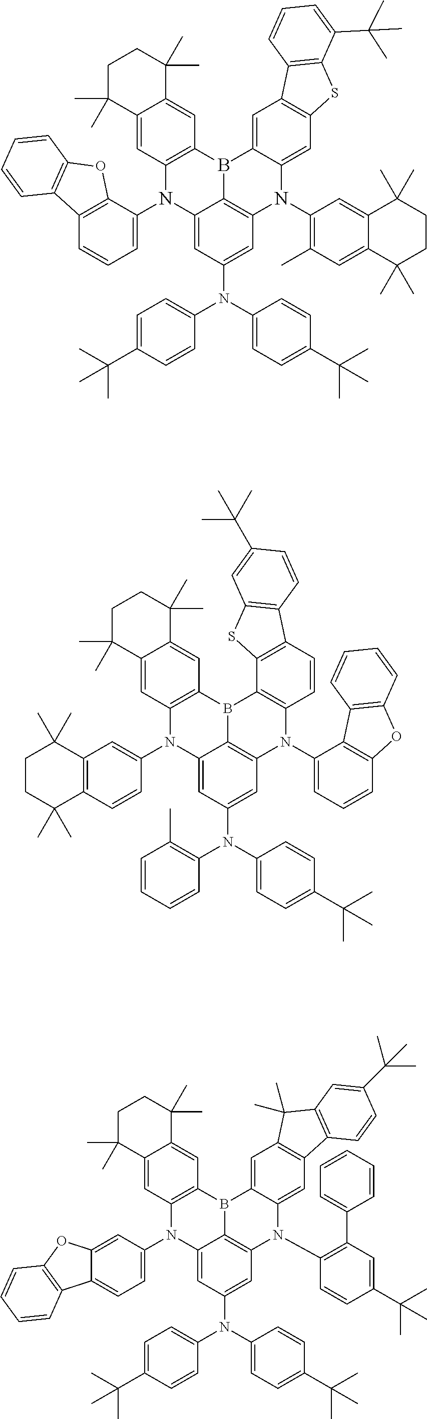 [SMILES: Cc1cc2c(cc1N1c3cc4sc5c(C(C)(C)C)cccc5c4cc3B3c4cc5c(cc4N(c4cccc6c4oc4ccccc46)c4cc(N(c6ccc(C(C)(C)C)cc6)c6ccc(C(C)(C)C)cc6)cc1c43)C(C)(C)CCC5(C)C)C(C)(C)CCC2(C)C ; Cc1ccccc1N(c1ccc(C(C)(C)C)cc1)c1cc2c3c(c1)N(c1cccc4oc5ccccc5c14)c1ccc4c(sc5cc(C(C)(C)C)ccc54)c1B3c1cc3c(cc1N2c1ccc2c(c1)C(C)(C)CCC2(C)C)C(C)(C)CCC3(C)C ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4c2cc4c(cc2N3c2ccc3c(c2)oc2ccccc23)C(C)(C)CCC4(C)C)C(C)(C)c2cc(C(C)(C)C)ccc2-5)cc1]

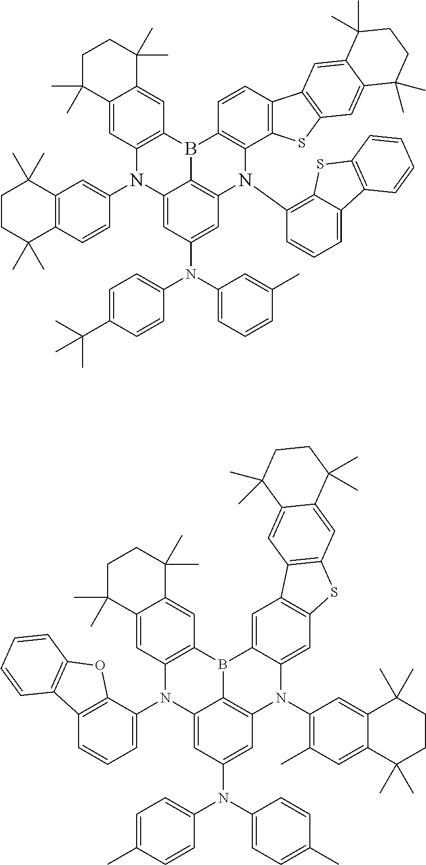 [SMILES: Cc1cccc(N(c2ccc(C(C)(C)C)cc2)c2cc3c4c(c2)N(c2cccc5c2sc2ccccc25)c2c(ccc5c2sc2cc6c(cc25)C(C)(C)CCC6(C)C)B4c2cc4c(cc2N3c2ccc3c(c2)C(C)(C)CCC3(C)C)C(C)(C)CCC4(C)C)c1 ; Cc1ccc(N(c2ccc(C)cc2)c2cc3c4c(c2)N(c2cccc5c2oc2ccccc25)c2cc5c(cc2B4c2cc4c(cc2N3c2cc3c(cc2C)C(C)(C)CCC3(C)C)sc2cc3c(cc24)C(C)(C)CCC3(C)C)C(C)(C)CCC5(C)C)cc1]

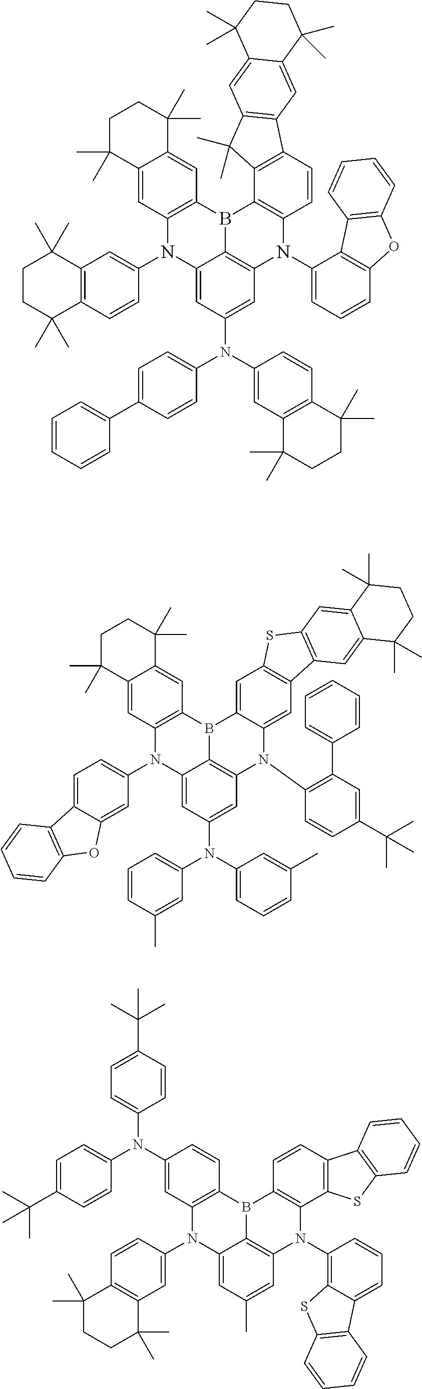

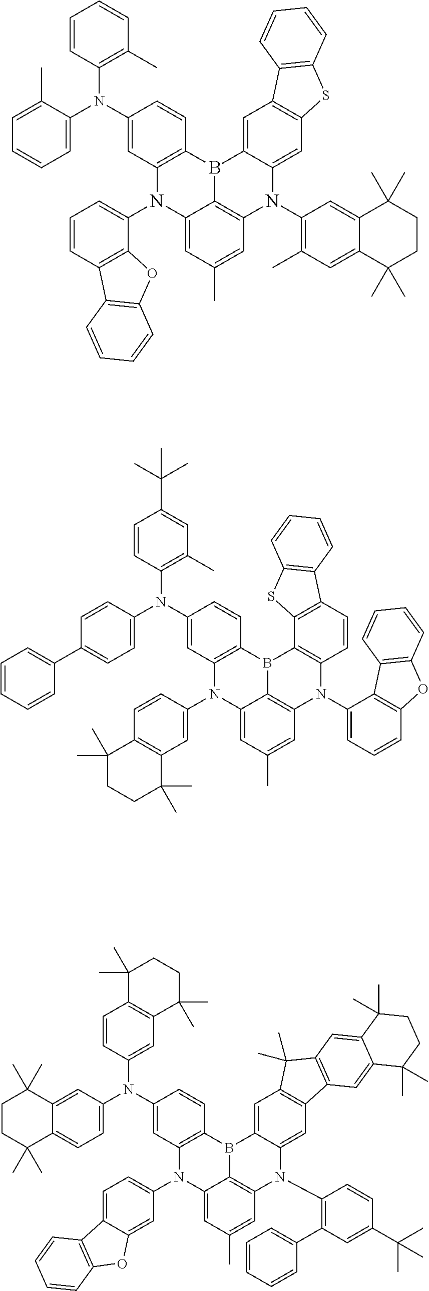 [SMILES: Cc1cc2c3c(c1)N(c1cccc4c1oc1ccccc14)c1cc(N(c4ccccc4C)c4ccccc4C)ccc1B3c1cc3c(cc1N2c1cc2c(cc1C)C(C)(C)CCC2(C)C)sc1ccccc13 ; Cc1cc2c3c(c1)N(c1cccc4oc5ccccc5c14)c1ccc4c(sc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)C(C)(C)c1cc2c(cc1-4)C(C)(C)CCC2(C)C]

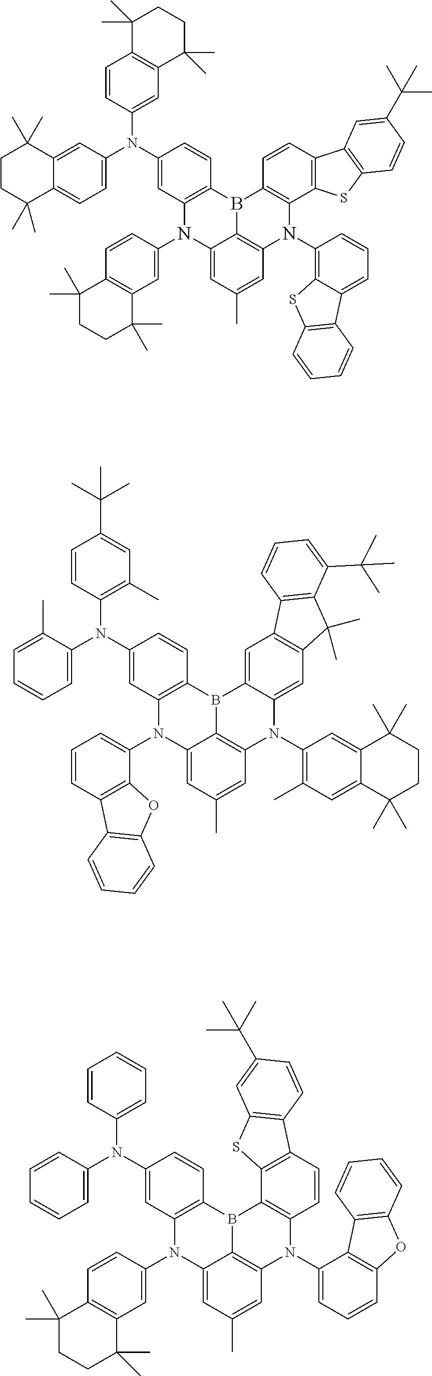

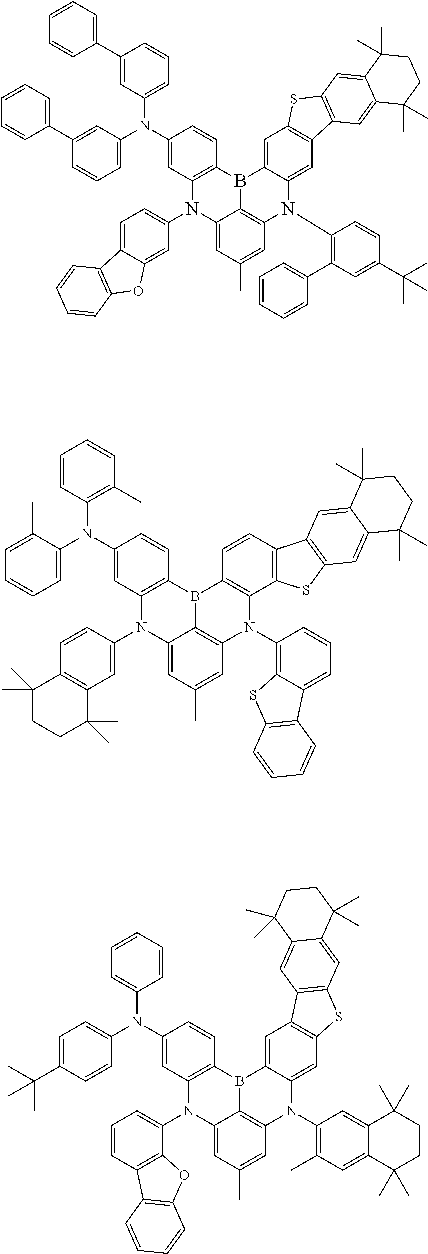

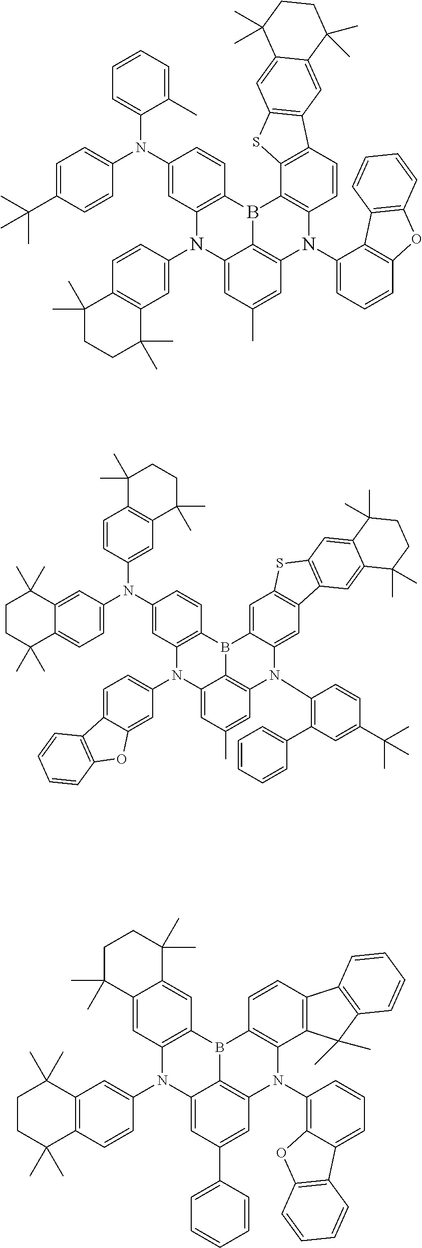 [SMILES: Cc1cc2c3c(c1)N(c1cccc4oc5ccccc5c14)c1ccc4c(sc5cc6c(cc54)C(C)(C)CCC6(C)C)c1B3c1ccc(N(c3ccc(C(C)(C)C)cc3)c3ccccc3C)cc1N2c1ccc2c(c1)C(C)(C)CCC2(C)C ; Cc1cc2c3c(c1)N(c1ccc(C(C)(C)C)cc1-c1ccccc1)c1cc4c(cc1B3c1ccc(N(c3ccc5c(c3)C(C)(C)CCC5(C)C)c3ccc5c(c3)C(C)(C)CCC5(C)C)cc1N2c1ccc2c(c1)oc1ccccc12)sc1cc2c(cc14)C(C)(C)CCC2(C)C ; CC1(C)CCC(C)(C)c2cc(N3c4cc5c(cc4B4c6ccc7c(c6N(c6cccc8c6oc6ccccc68)c6cc(-c8ccccc8)cc3c64)C(C)(C)c3ccccc3-7)C(C)(C)CCC5(C)C)ccc21]

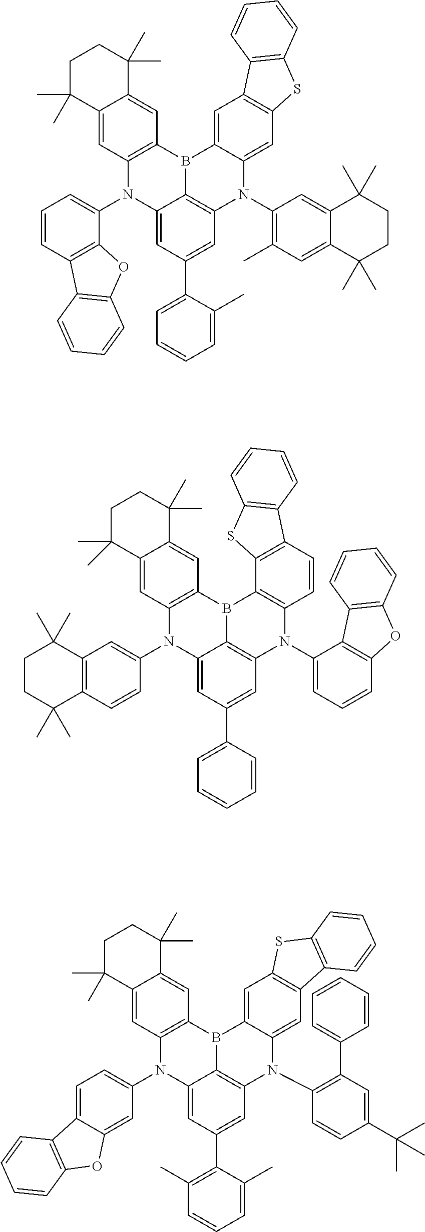 [SMILES: Cc1ccccc1-c1cc2c3c(c1)N(c1cccc4c1oc1ccccc14)c1cc4c(cc1B3c1cc3c(cc1N2c1cc2c(cc1C)C(C)(C)CCC2(C)C)sc1ccccc13)C(C)(C)CCC4(C)C ; CC1(C)CCC(C)(C)c2cc(N3c4cc5c(cc4B4c6c3cc(-c3ccccc3)cc6N(c3cccc6oc7ccccc7c36)c3ccc6c(sc7ccccc76)c34)C(C)(C)CCC5(C)C)ccc21 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)sc1ccccc14]

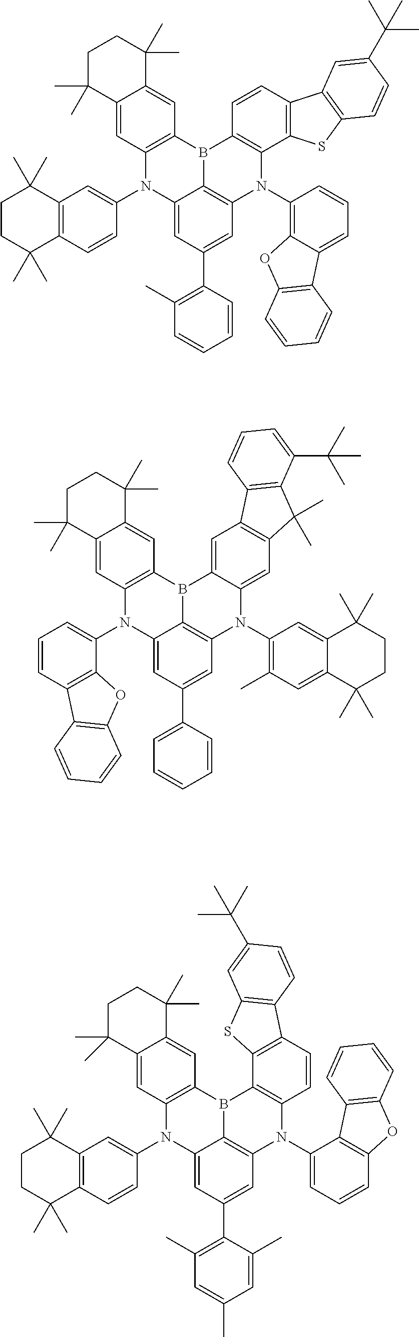

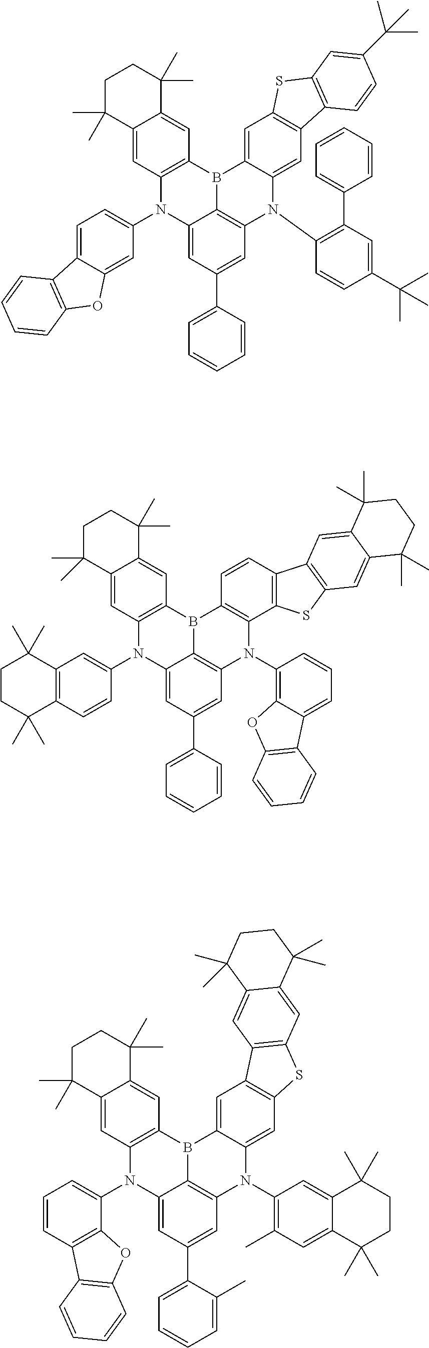

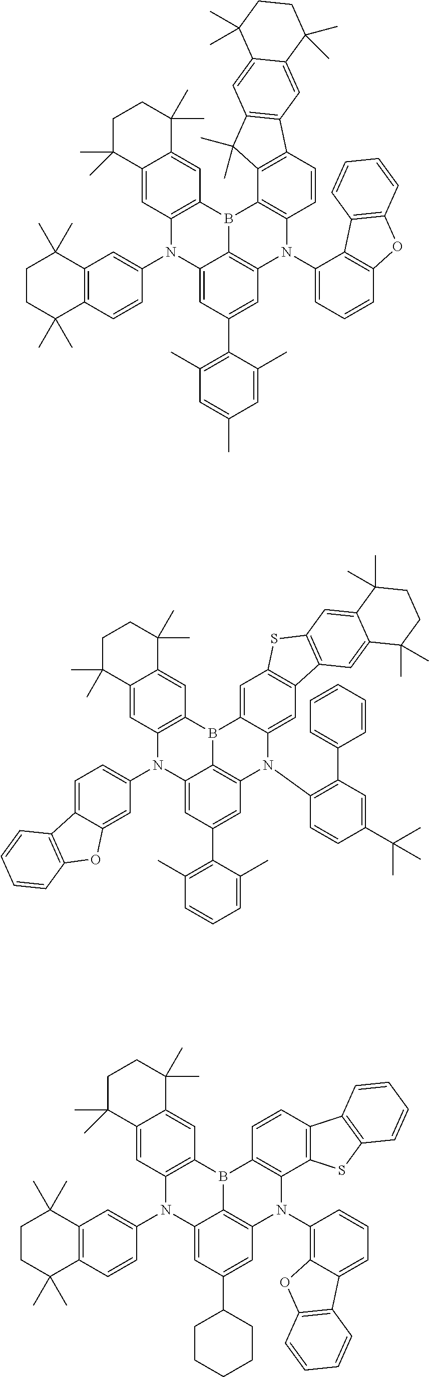 [SMILES: Cc1cc(C)c(-c2cc3c4c(c2)N(c2cccc5oc6ccccc6c25)c2ccc5c(c2B4c2cc4c(cc2N3c2ccc3c(c2)C(C)(C)CCC3(C)C)C(C)(C)CCC4(C)C)C(C)(C)c2cc3c(cc2-5)C(C)(C)CCC3(C)C)c(C)c1 ; Cc1cccc(C)c1-c1cc2c3c(c1)N(c1ccc(C(C)(C)C)cc1-c1ccccc1)c1cc4c(cc1B3c1cc3c(cc1N2c1ccc2c(c1)oc1ccccc12)C(C)(C)CCC3(C)C)sc1cc2c(cc14)C(C)(C)CCC2(C)C ; CC1(C)CCC(C)(C)c2cc(N3c4cc5c(cc4B4c6ccc7c(sc8ccccc87)c6N(c6cccc7c6oc6ccccc67)c6cc(C7CCCCC7)cc3c64)C(C)(C)CCC5(C)C)ccc21]

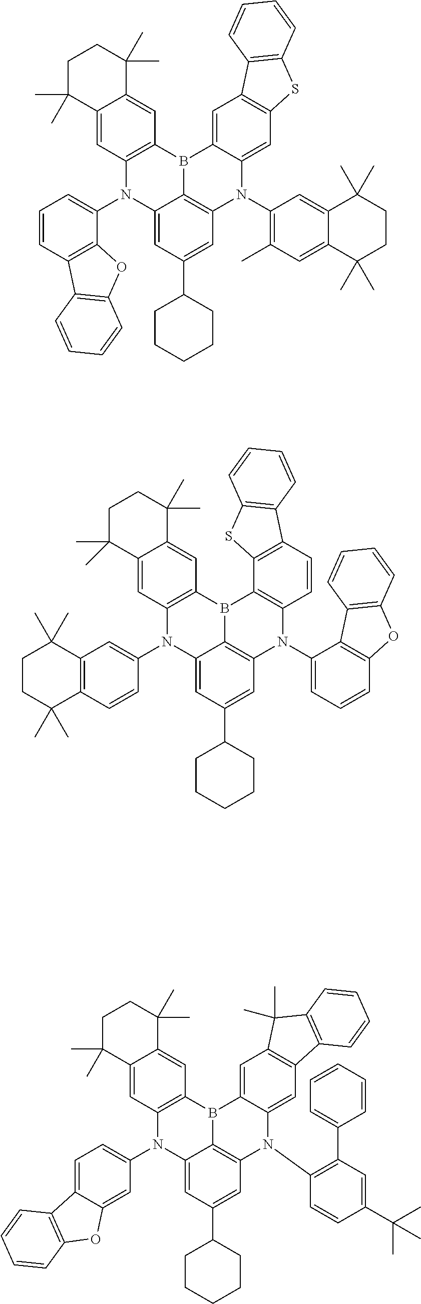 [SMILES: Cc1cc2c(cc1N1c3cc4sc5ccccc5c4cc3B3c4cc5c(cc4N(c4cccc6c4oc4ccccc46)c4cc(C6CCCCC6)cc1c43)C(C)(C)CCC5(C)C)C(C)(C)CCC2(C)C ; CC1(C)CCC(C)(C)c2cc(N3c4cc5c(cc4B4c6c3cc(C3CCCCC3)cc6N(c3cccc6oc7ccccc7c36)c3ccc6c(sc7ccccc76)c34)C(C)(C)CCC5(C)C)ccc21 ; CC(C)(C)c1ccc(N2c3cc4c(cc3B3c5cc6c(cc5N(c5ccc7c(c5)oc5ccccc57)c5cc(C7CCCCC7)cc2c53)C(C)(C)CCC6(C)C)C(C)(C)c2ccccc2-4)c(-c2ccccc2)c1]

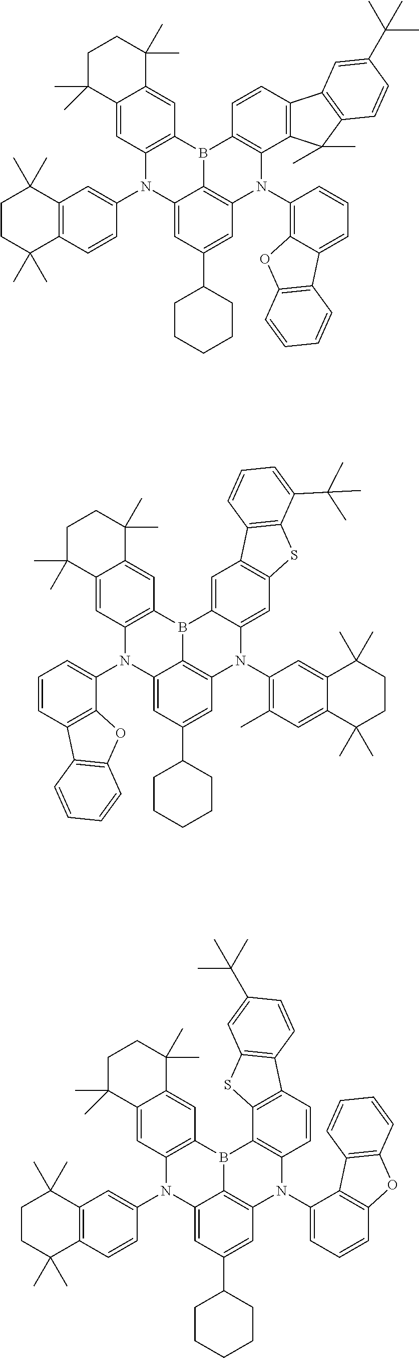

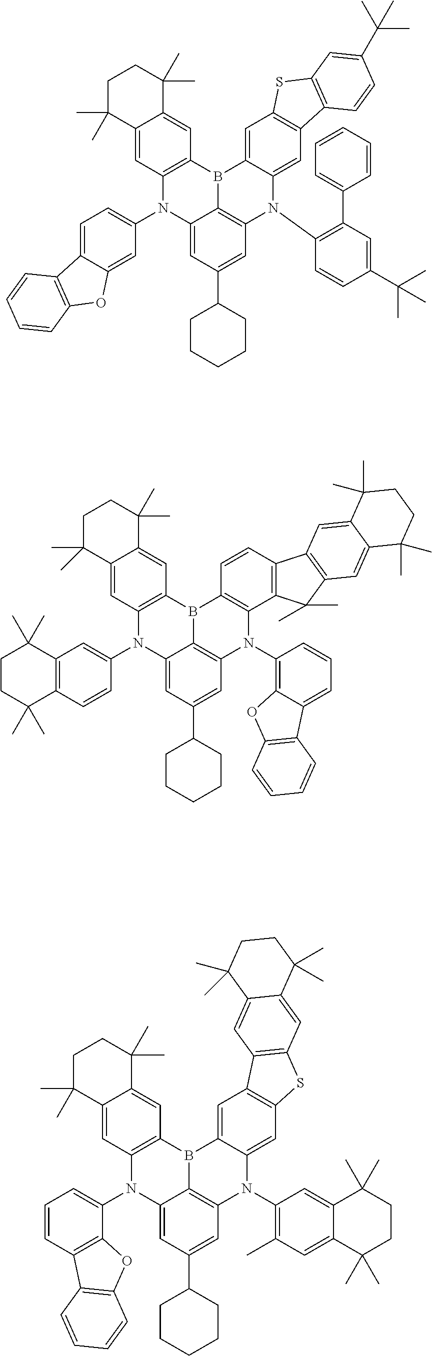

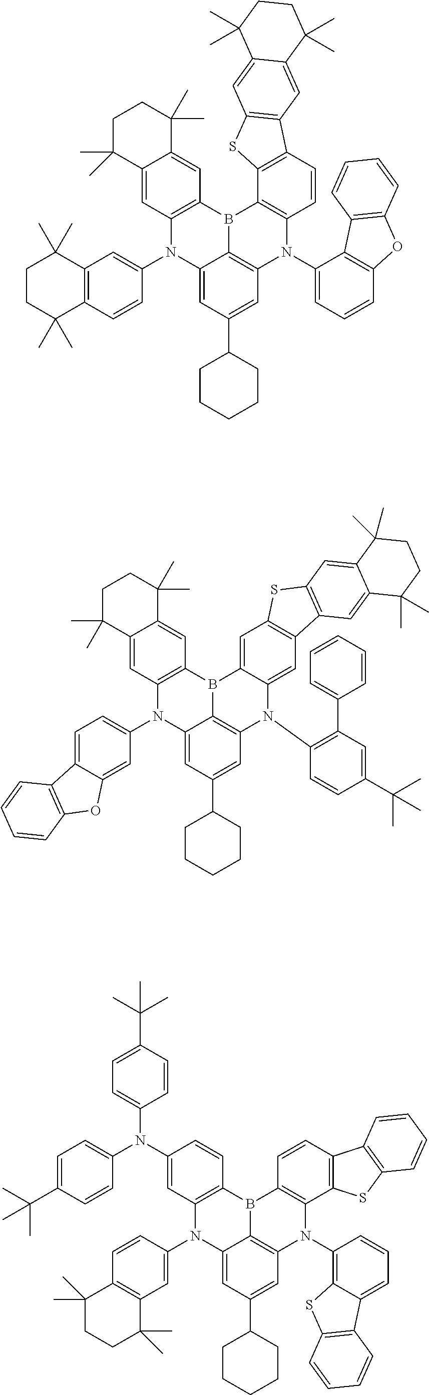

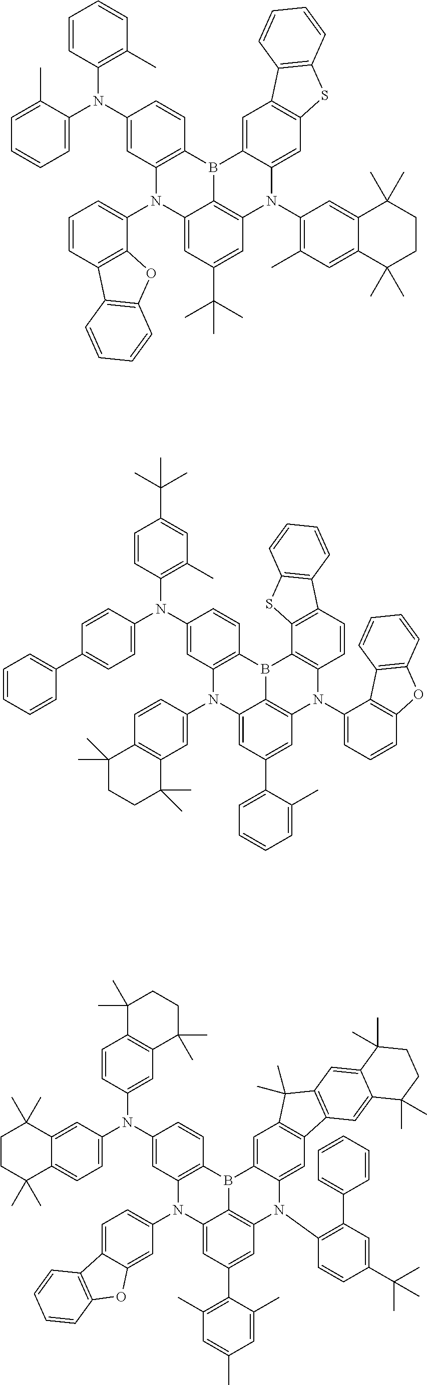 [SMILES: Cc1ccccc1N(c1ccc2c(c1)N(c1cccc3c1oc1ccccc13)c1cc(C(C)(C)C)cc3c1B2c1cc2c(cc1N3c1cc3c(cc1C)C(C)(C)CCC3(C)C)sc1ccccc12)c1ccccc1C ; Cc1ccccc1-c1cc2c3c(c1)N(c1cccc4oc5ccccc5c14)c1ccc4c(sc5ccccc54)c1B3c1ccc(N(c3ccc(-c4ccccc4)cc3)c3ccc(C(C)(C)C)cc3C)cc1N2c1ccc2c(c1)C(C)(C)CCC2(C)C ; Cc1cc(C)c(-c2cc3c4c(c2)N(c2ccc(C(C)(C)C)cc2-c2ccccc2)c2cc5c(cc2B4c2ccc(N(c4ccc6c(c4)C(C)(C)CCC6(C)C)c4ccc6c(c4)C(C)(C)CCC6(C)C)cc2N3c2ccc3c(c2)oc2ccccc23)C(C)(C)c2cc3c(cc2-5)C(C)(C)CCC3(C)C)c(C)c1]

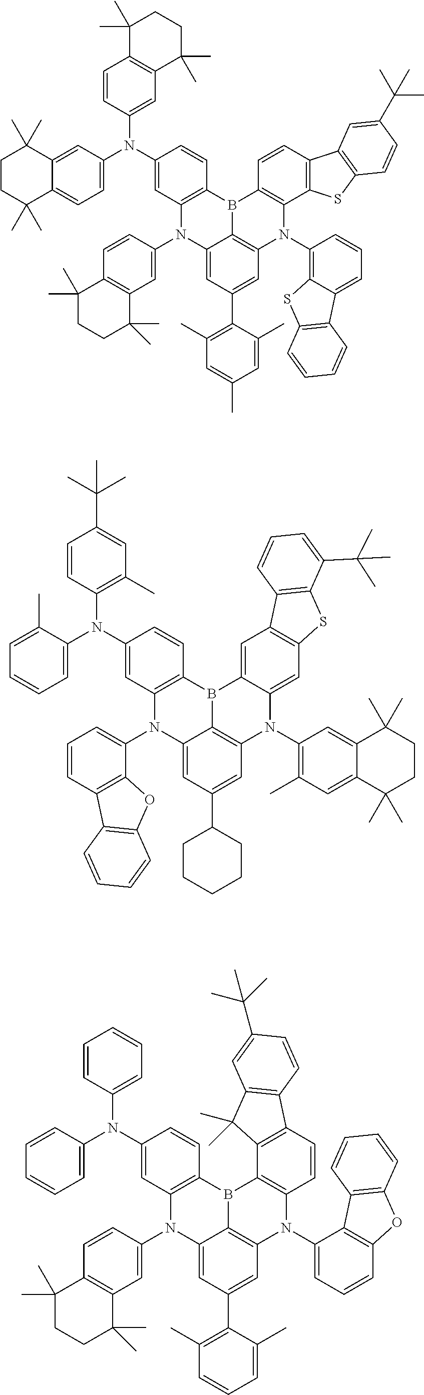

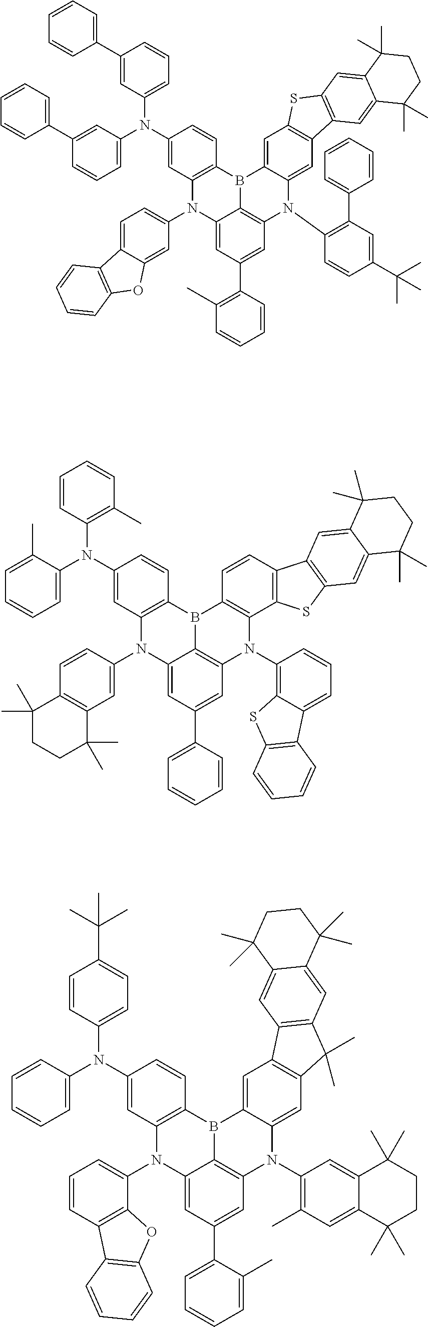

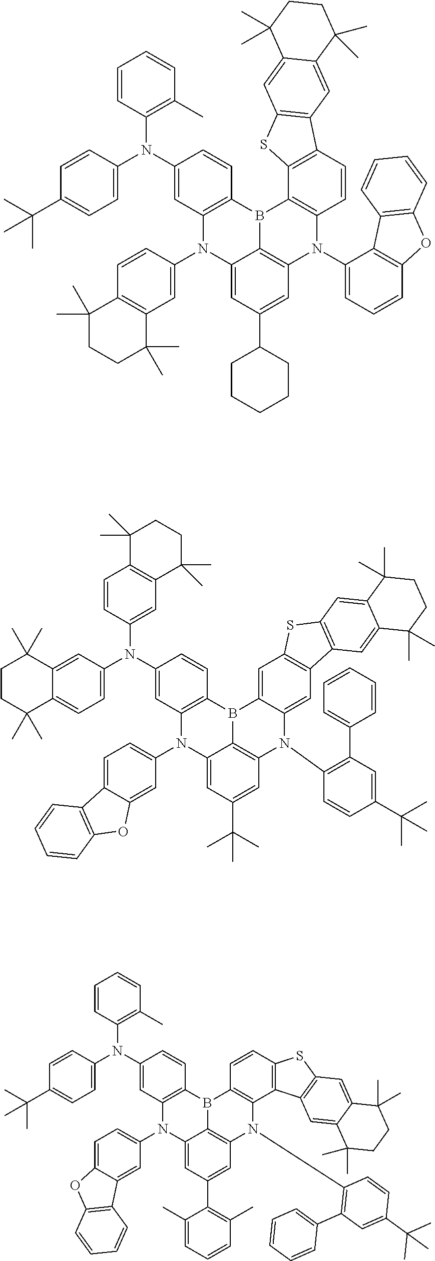

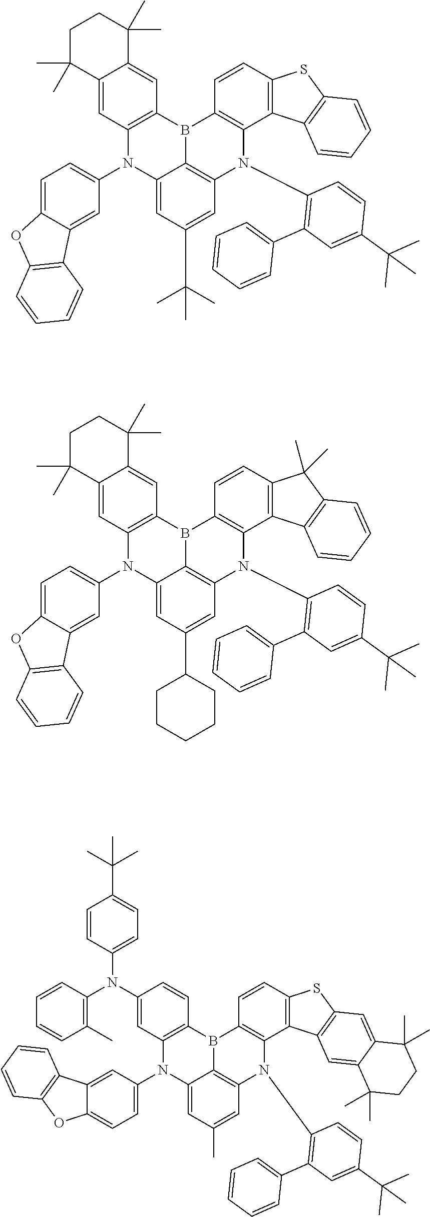 [SMILES: CC(C)(C)c1ccc(N2c3cc(C(C)(C)C)cc4c3B(c3cc5c(cc3N4c3ccc4oc6ccccc6c4c3)C(C)(C)CCC5(C)C)c3ccc4sc5ccccc5c4c32)c(-c2ccccc2)c1 ; CC(C)(C)c1ccc(N2c3cc(C4CCCCC4)cc4c3B(c3cc5c(cc3N4c3ccc4oc6ccccc6c4c3)C(C)(C)CCC5(C)C)c3ccc4c(c32)-c2ccccc2C4(C)C)c(-c2ccccc2)c1 ; Cc1cc2c3c(c1)N(c1ccc(C(C)(C)C)cc1-c1ccccc1)c1c(ccc4sc5cc6c(cc5c14)C(C)(C)CCC6(C)C)B3c1ccc(N(c3ccc(C(C)(C)C)cc3)c3ccccc3C)cc1N2c1ccc2oc3ccccc3c2c1]

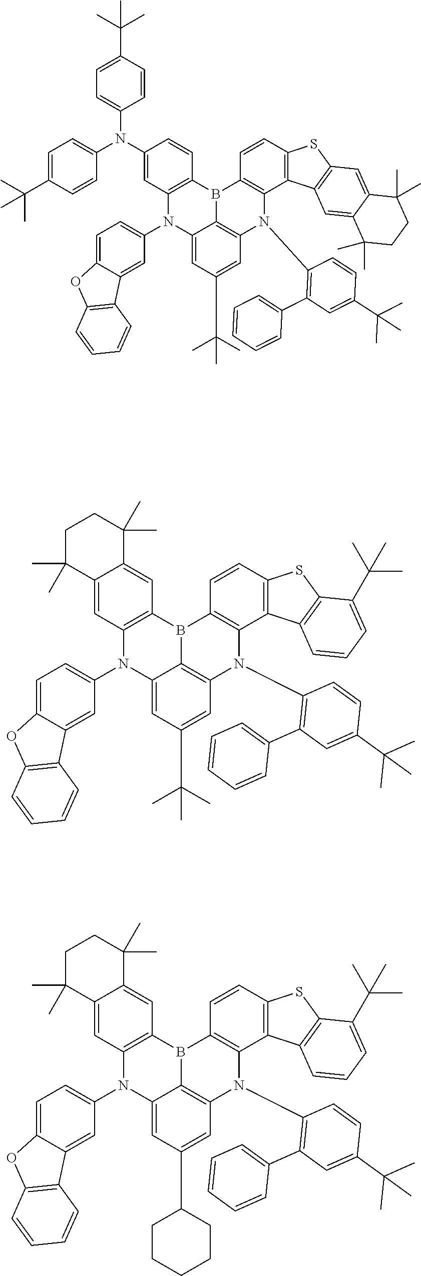 [SMILES: CC(C)(C)c1ccc(N(c2ccc(C(C)(C)C)cc2)c2ccc3c(c2)N(c2ccc4oc5ccccc5c4c2)c2cc(C(C)(C)C)cc4c2B3c2ccc3sc5cc6c(cc5c3c2N4c2ccc(C(C)(C)C)cc2-c2ccccc2)C(C)(C)CCC6(C)C)cc1 ; CC(C)(C)c1ccc(N2c3cc(C(C)(C)C)cc4c3B(c3cc5c(cc3N4c3ccc4oc6ccccc6c4c3)C(C)(C)CCC5(C)C)c3ccc4sc5c(C(C)(C)C)cccc5c4c32)c(-c2ccccc2)c1 ; CC(C)(C)c1ccc(N2c3cc(C4CCCCC4)cc4c3B(c3cc5c(cc3N4c3ccc4oc6ccccc6c4c3)C(C)(C)CCC5(C)C)c3ccc4sc5c(C(C)(C)C)cccc5c4c32)c(-c2ccccc2)c1]

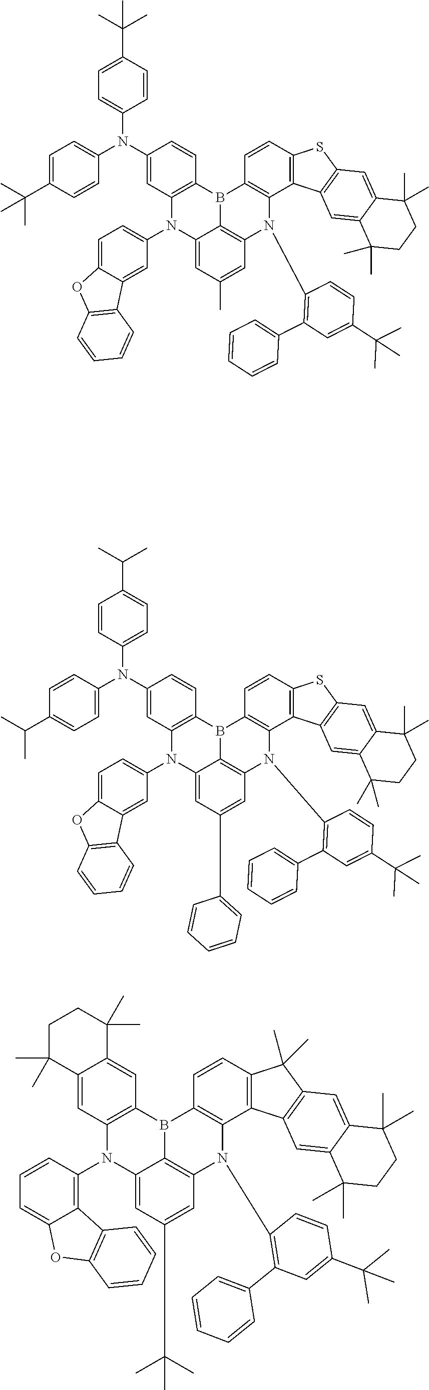

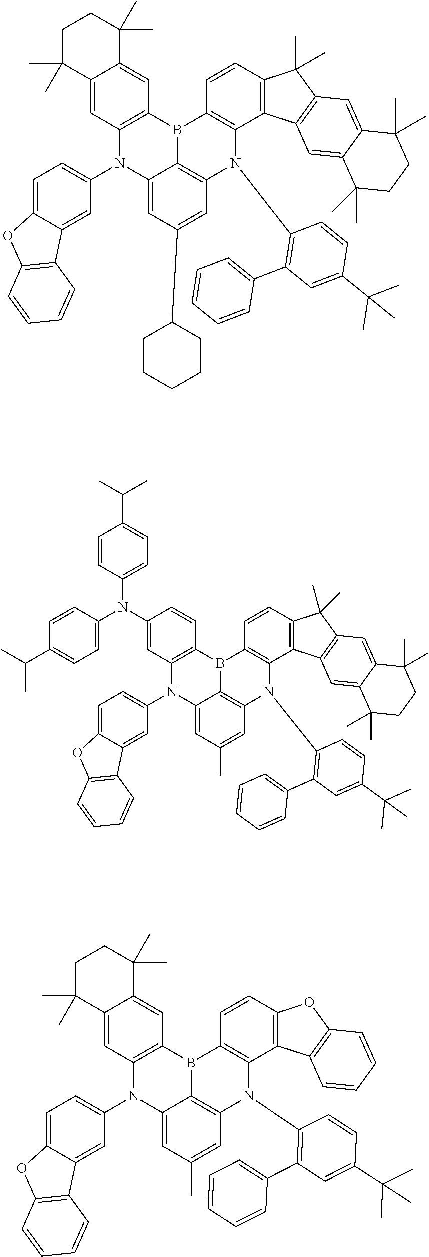

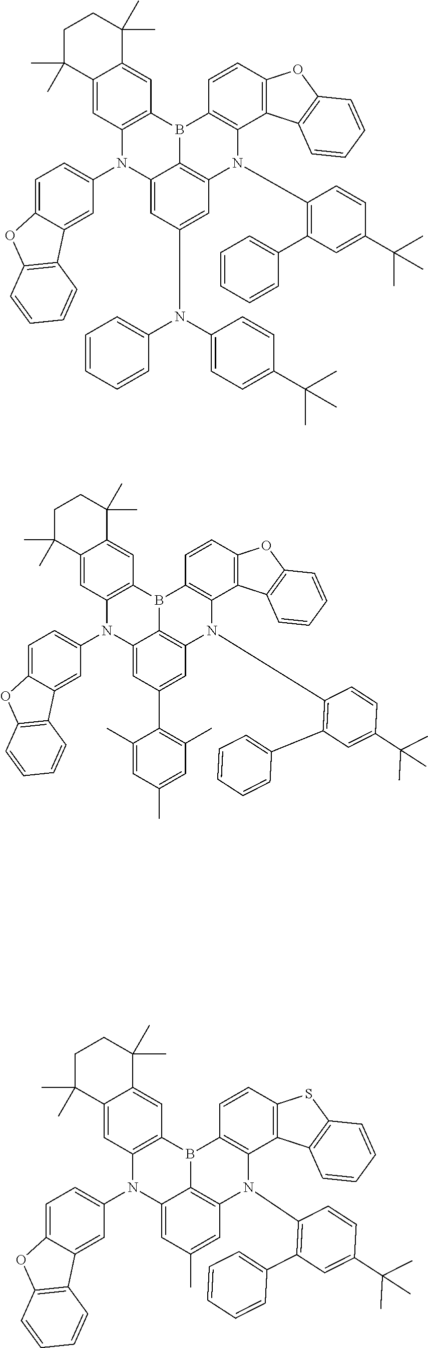 [SMILES: CC(C)(C)c1ccc(N(c2ccccc2)c2cc3c4c(c2)N(c2ccc(C(C)(C)C)cc2-c2ccccc2)c2c(ccc5oc6ccccc6c25)B4c2cc4c(cc2N3c2ccc3oc5ccccc5c3c2)C(C)(C)CCC4(C)C)cc1 ; Cc1cc(C)c(-c2cc3c4c(c2)N(c2ccc(C(C)(C)C)cc2-c2ccccc2)c2c(ccc5oc6ccccc6c25)B4c2cc4c(cc2N3c2ccc3oc5ccccc5c3c2)C(C)(C)CCC4(C)C)c(C)c1 ; Cc1cc2c3c(c1)N(c1ccc(C(C)(C)C)cc1-c1ccccc1)c1c(ccc4sc5ccccc5c14)B3c1cc3c(cc1N2c1ccc2oc4ccccc4c2c1)C(C)(C)CCC3(C)C]

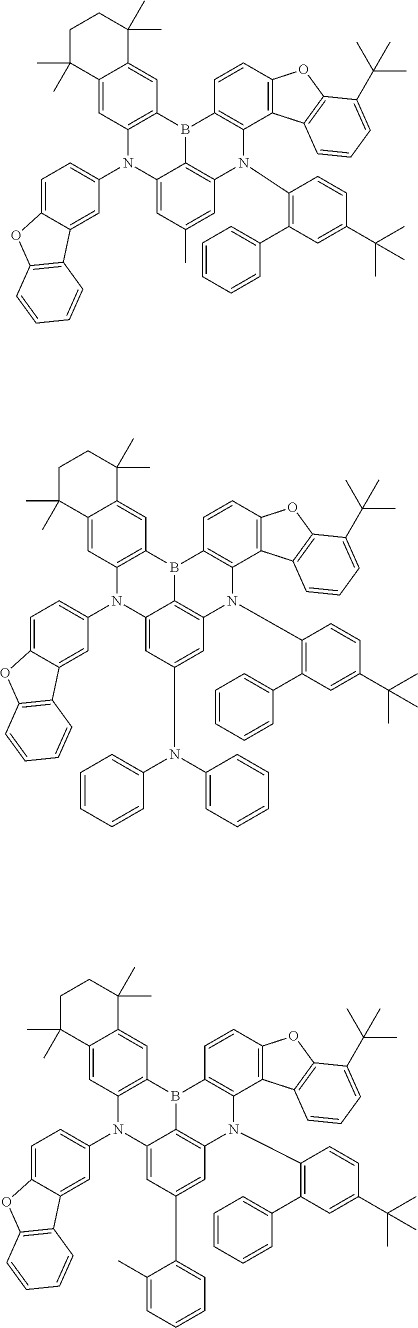 [SMILES: Cc1cc2c3c(c1)N(c1ccc(C(C)(C)C)cc1-c1ccccc1)c1c(ccc4oc5c(C(C)(C)C)cccc5c14)B3c1cc3c(cc1N2c1ccc2oc4ccccc4c2c1)C(C)(C)CCC3(C)C ; CC(C)(C)c1ccc(N2c3cc(N(c4ccccc4)c4ccccc4)cc4c3B(c3cc5c(cc3N4c3ccc4oc6ccccc6c4c3)C(C)(C)CCC5(C)C)c3ccc4oc5c(C(C)(C)C)cccc5c4c32)c(-c2ccccc2)c1 ; Cc1ccccc1-c1cc2c3c(c1)N(c1ccc(C(C)(C)C)cc1-c1ccccc1)c1c(ccc4oc5c(C(C)(C)C)cccc5c14)B3c1cc3c(cc1N2c1ccc2oc4ccccc4c2c1)C(C)(C)CCC3(C)C]

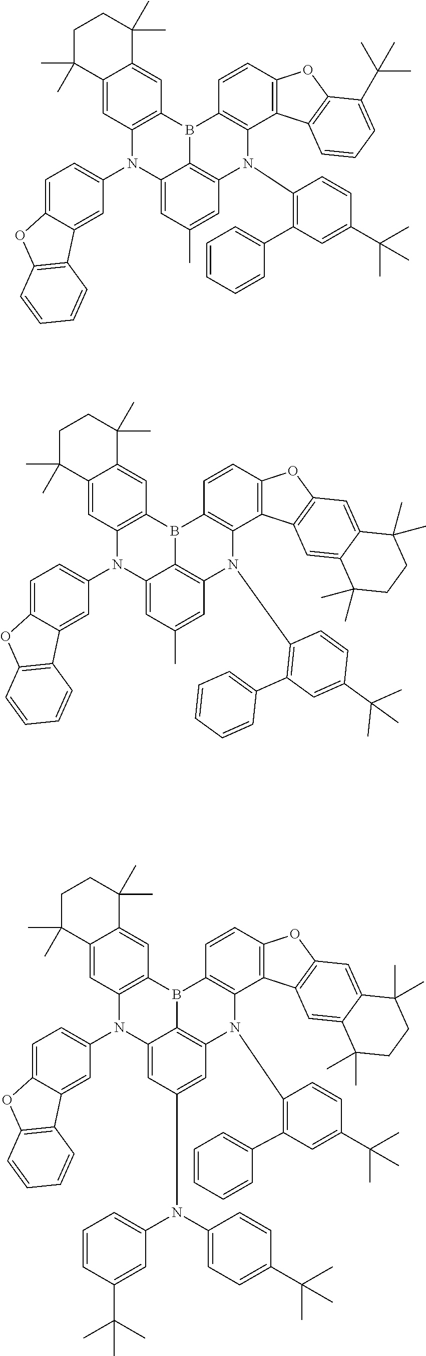 [SMILES: Cc1cc2c3c(c1)N(c1ccc(C(C)(C)C)cc1-c1ccccc1)c1c(ccc4oc5c(C(C)(C)C)cccc5c14)B3c1cc3c(cc1N2c1ccc2oc4ccccc4c2c1)C(C)(C)CCC3(C)C ; Cc1cc2c3c(c1)N(c1ccc(C(C)(C)C)cc1-c1ccccc1)c1c(ccc4oc5cc6c(cc5c14)C(C)(C)CCC6(C)C)B3c1cc3c(cc1N2c1ccc2oc4ccccc4c2c1)C(C)(C)CCC3(C)C ; CC(C)(C)c1ccc(N(c2cccc(C(C)(C)C)c2)c2cc3c4c(c2)N(c2ccc(C(C)(C)C)cc2-c2ccccc2)c2c(ccc5oc6cc7c(cc6c25)C(C)(C)CCC7(C)C)B4c2cc4c(cc2N3c2ccc3oc5ccccc5c3c2)C(C)(C)CCC4(C)C)cc1]

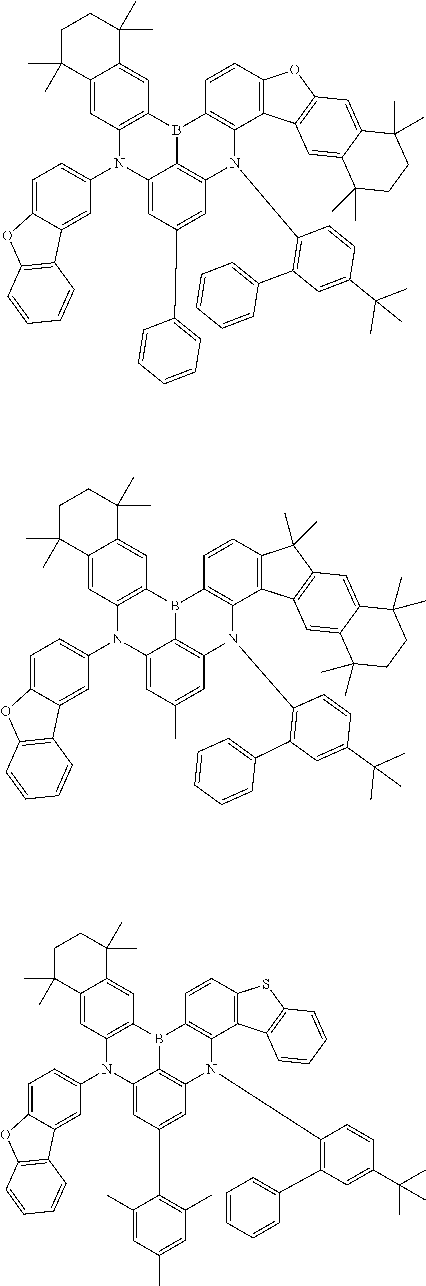 [SMILES: CC(C)(C)c1ccc(N2c3cc(-c4ccccc4)cc4c3B(c3cc5c(cc3N4c3ccc4oc6ccccc6c4c3)C(C)(C)CCC5(C)C)c3ccc4oc5cc6c(cc5c4c32)C(C)(C)CCC6(C)C)c(-c2ccccc2)c1 ; Cc1cc2c3c(c1)N(c1ccc(C(C)(C)C)cc1-c1ccccc1)c1c(ccc4c1-c1cc5c(cc1C4(C)C)C(C)(C)CCC5(C)C)B3c1cc3c(cc1N2c1ccc2oc4ccccc4c2c1)C(C)(C)CCC3(C)C ; Cc1cc(C)c(-c2cc3c4c(c2)N(c2ccc(C(C)(C)C)cc2-c2ccccc2)c2c(ccc5sc6ccccc6c25)B4c2cc4c(cc2N3c2ccc3oc5ccccc5c3c2)C(C)(C)CCC4(C)C)c(C)c1]

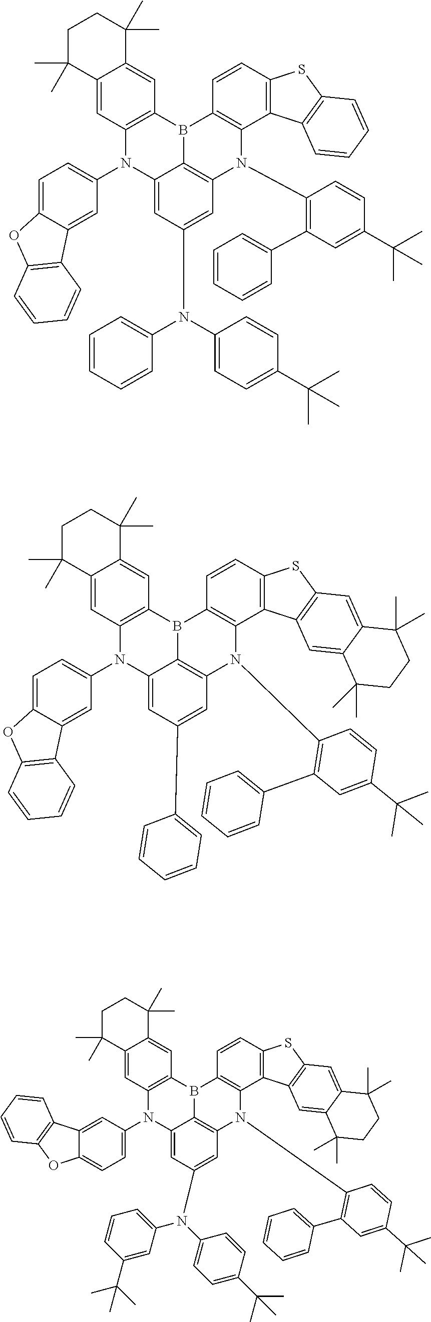 [SMILES: CC(C)(C)c1ccc(N(c2ccccc2)c2cc3c4c(c2)N(c2ccc(C(C)(C)C)cc2-c2ccccc2)c2c(ccc5sc6ccccc6c25)B4c2cc4c(cc2N3c2ccc3oc5ccccc5c3c2)C(C)(C)CCC4(C)C)cc1 ; CC(C)(C)c1ccc(N2c3cc(-c4ccccc4)cc4c3B(c3cc5c(cc3N4c3ccc4oc6ccccc6c4c3)C(C)(C)CCC5(C)C)c3ccc4sc5cc6c(cc5c4c32)C(C)(C)CCC6(C)C)c(-c2ccccc2)c1 ; CC(C)(C)c1ccc(N(c2cccc(C(C)(C)C)c2)c2cc3c4c(c2)N(c2ccc(C(C)(C)C)cc2-c2ccccc2)c2c(ccc5sc6cc7c(cc6c25)C(C)(C)CCC7(C)C)B4c2cc4c(cc2N3c2ccc3oc5ccccc5c3c2)C(C)(C)CCC4(C)C)cc1]

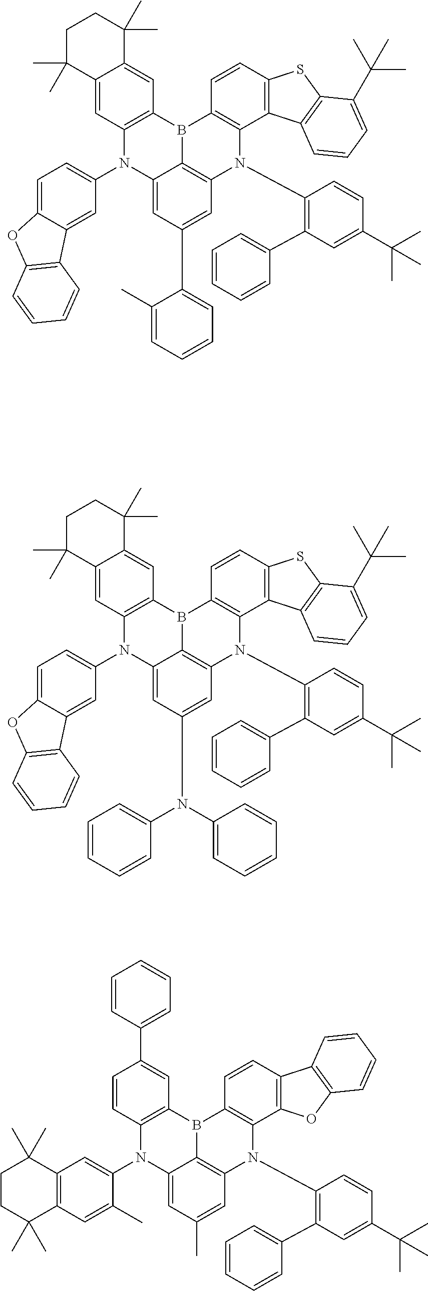 [SMILES: Cc1ccccc1-c1cc2c3c(c1)N(c1ccc(C(C)(C)C)cc1-c1ccccc1)c1c(ccc4sc5c(C(C)(C)C)cccc5c14)B3c1cc3c(cc1N2c1ccc2oc4ccccc4c2c1)C(C)(C)CCC3(C)C ; CC(C)(C)c1ccc(N2c3cc(N(c4ccccc4)c4ccccc4)cc4c3B(c3cc5c(cc3N4c3ccc4oc6ccccc6c4c3)C(C)(C)CCC5(C)C)c3ccc4sc5c(C(C)(C)C)cccc5c4c32)c(-c2ccccc2)c1 ; Cc1cc2c3c(c1)N(c1ccc(C(C)(C)C)cc1-c1ccccc1)c1c(ccc4c1oc1ccccc14)B3c1cc(-c3ccccc3)ccc1N2c1cc2c(cc1C)C(C)(C)CCC2(C)C]

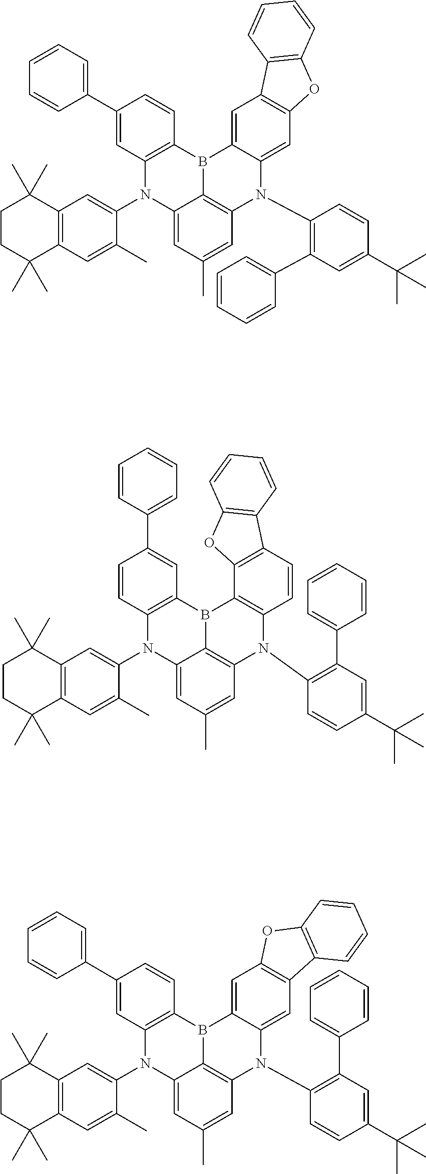 [SMILES: Cc1cc2c3c(c1)N(c1ccc(C(C)(C)C)cc1-c1ccccc1)c1cc4oc5ccccc5c4cc1B3c1ccc(-c3ccccc3)cc1N2c1cc2c(cc1C)C(C)(C)CCC2(C)C ; Cc1cc2c3c(c1)N(c1ccc(C(C)(C)C)cc1-c1ccccc1)c1ccc4c(oc5ccccc54)c1B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3ccccc3)cc1N2c1cc2c(cc1C)C(C)(C)CCC2(C)C)oc1ccccc14]

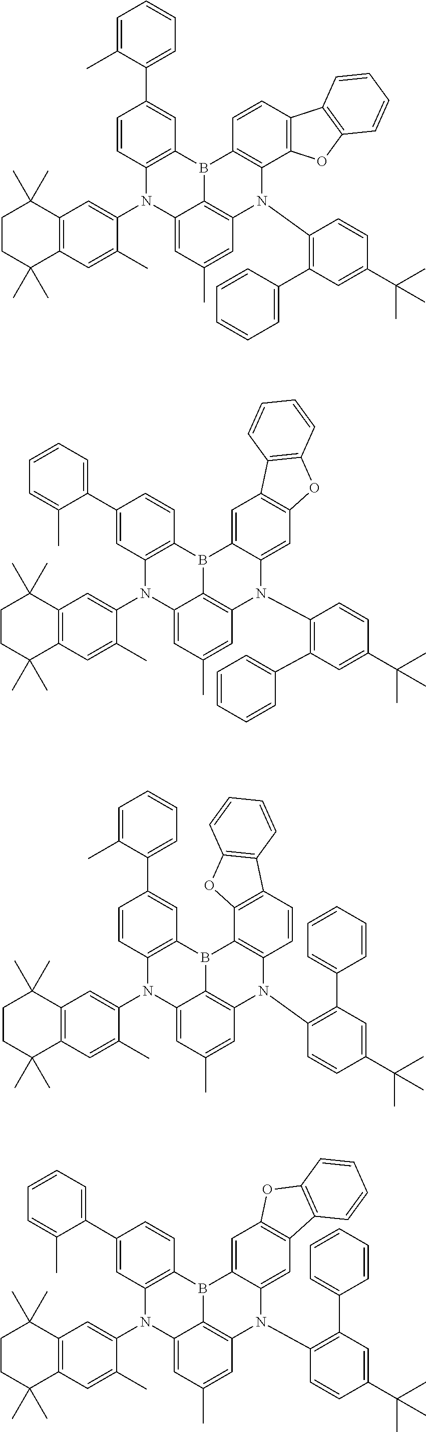 [SMILES: Cc1cc2c3c(c1)N(c1ccc(C(C)(C)C)cc1-c1ccccc1)c1c(ccc4c1oc1ccccc14)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4oc5ccccc5c4cc1B3c1ccc(-c3ccccc3C)cc1N2c1cc2c(cc1C)C(C)(C)CCC2(C)C ; Cc1cc2c3c(c1)N(c1ccc(C(C)(C)C)cc1-c1ccccc1)c1ccc4c(oc5ccccc54)c1B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3ccccc3C)cc1N2c1cc2c(cc1C)C(C)(C)CCC2(C)C)oc1ccccc14]

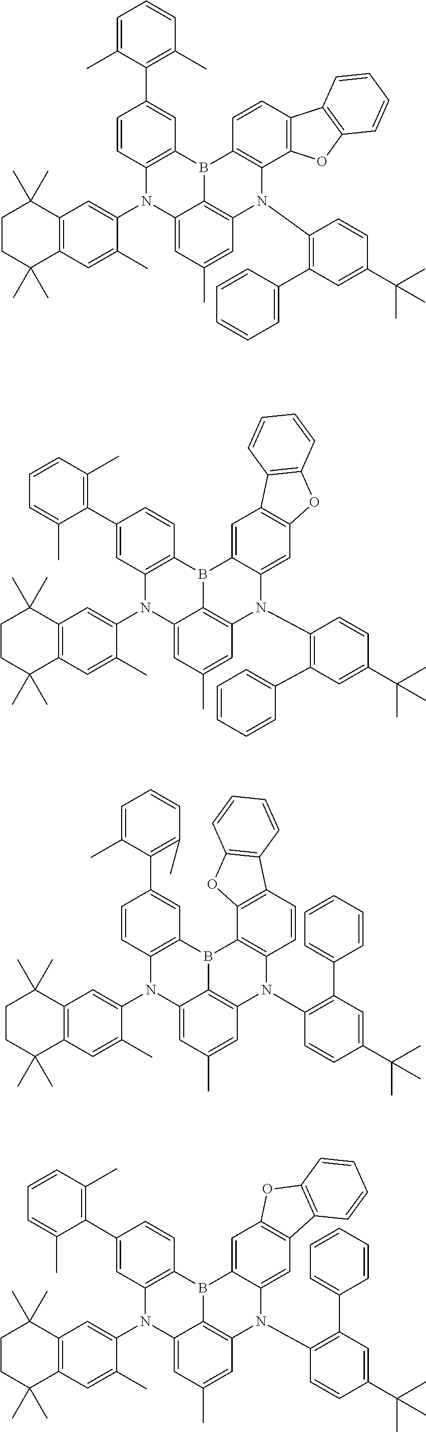 [SMILES: Cc1cc2c3c(c1)N(c1ccc(C(C)(C)C)cc1-c1ccccc1)c1c(ccc4c1oc1ccccc14)B3c1cc(-c3c(C)cccc3C)ccc1N2c1cc2c(cc1C)C(C)(C)CCC2(C)C ; Cc1cc2c3c(c1)N(c1ccc(C(C)(C)C)cc1-c1ccccc1)c1cc4oc5ccccc5c4cc1B3c1ccc(-c3c(C)cccc3C)cc1N2c1cc2c(cc1C)C(C)(C)CCC2(C)C ; Cc1cc2c3c(c1)N(c1ccc(C(C)(C)C)cc1-c1ccccc1)c1ccc4c(oc5ccccc54)c1B3c1cc(-c3c(C)cccc3C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3c(C)cccc3C)cc1N2c1cc2c(cc1C)C(C)(C)CCC2(C)C)oc1ccccc14]

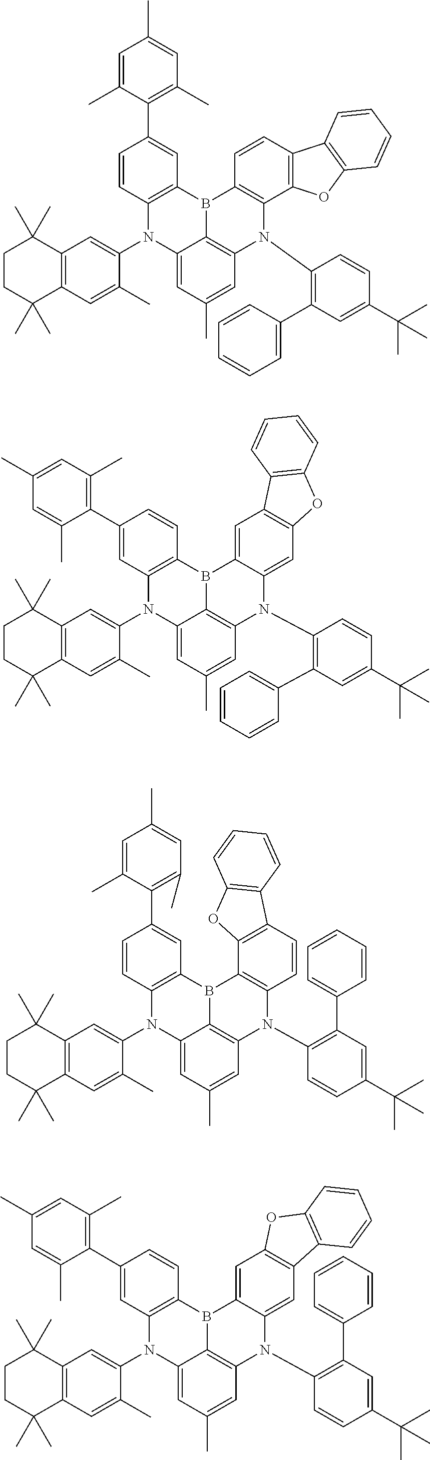

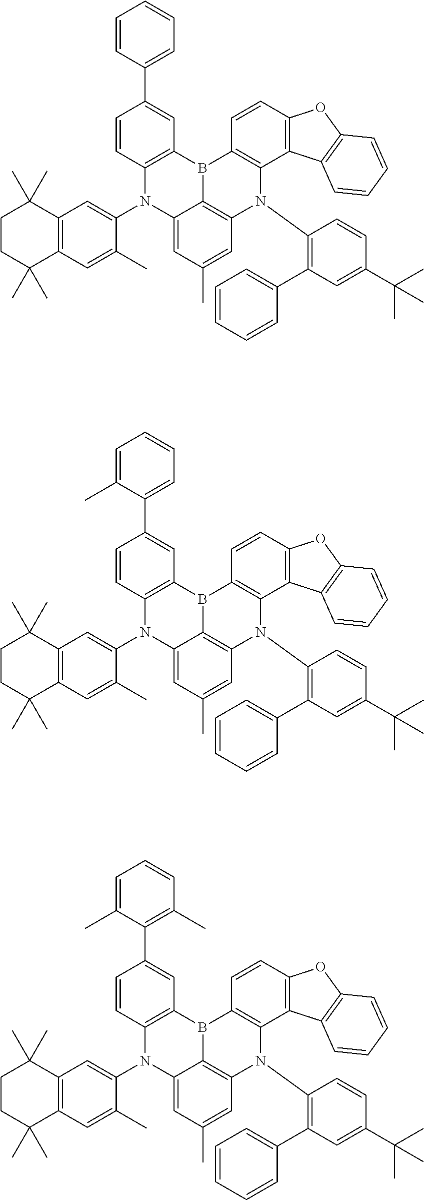 [SMILES: Cc1cc2c3c(c1)N(c1ccc(C(C)(C)C)cc1-c1ccccc1)c1c(ccc4oc5ccccc5c14)B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1c(ccc4oc5ccccc5c14)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1c(ccc4oc5ccccc5c14)B3c1cc(-c3c(C)cccc3C)ccc1N2c1cc2c(cc1C)C(C)(C)CCC2(C)C]

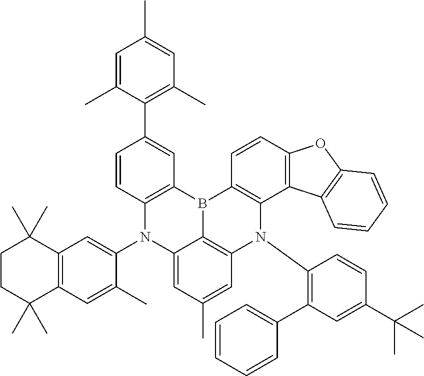 [SMILES: Cc1cc(C)c(-c2ccc3c(c2)B2c4ccc5oc6ccccc6c5c4N(c4ccc(C(C)(C)C)cc4-c4ccccc4)c4cc(C)cc(c42)N3c2cc3c(cc2C)C(C)(C)CCC3(C)C)c(C)c1]

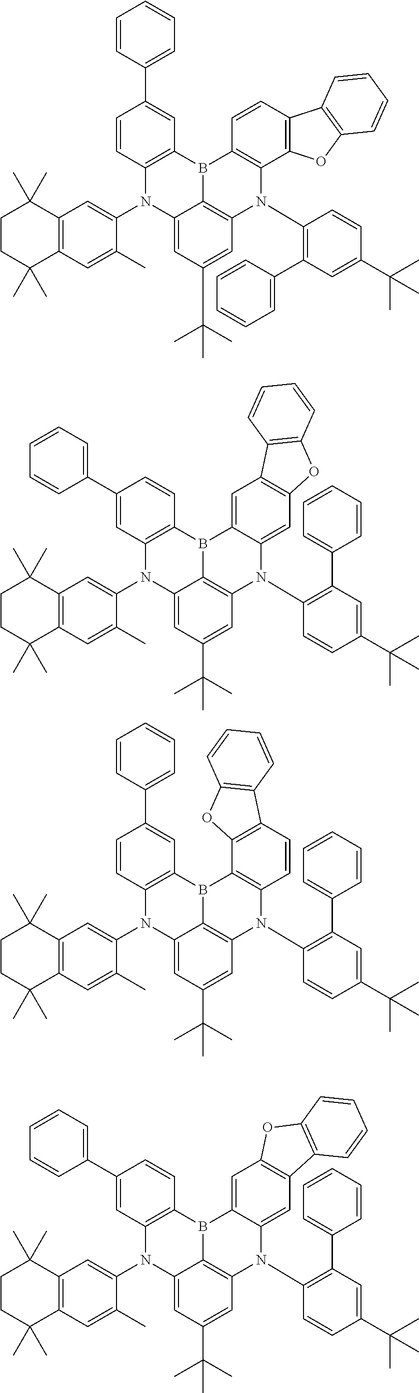

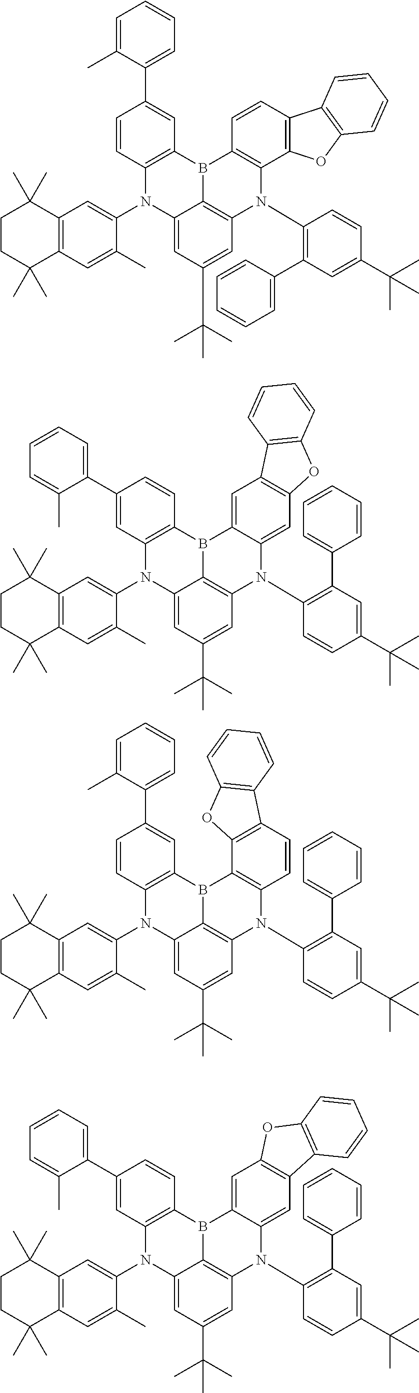

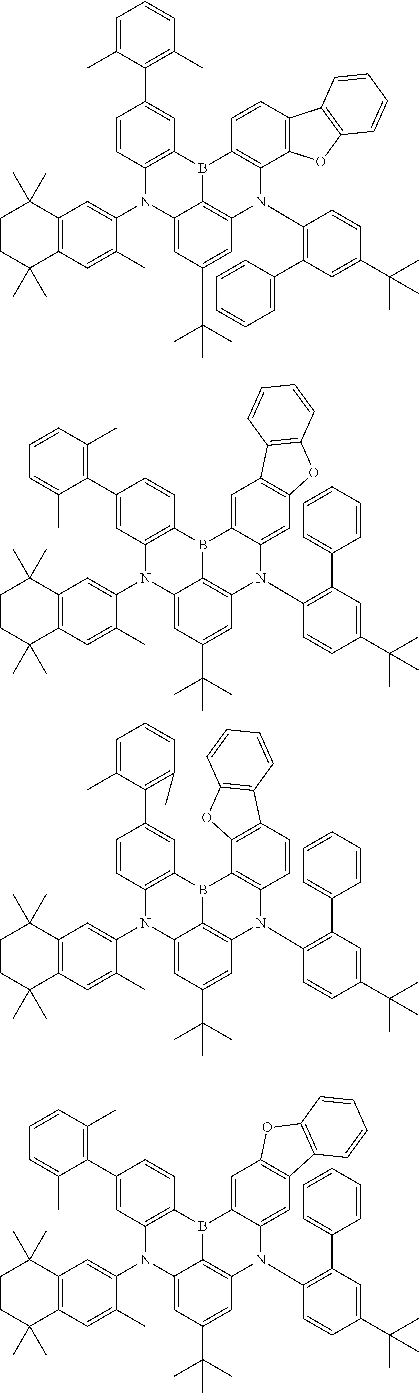

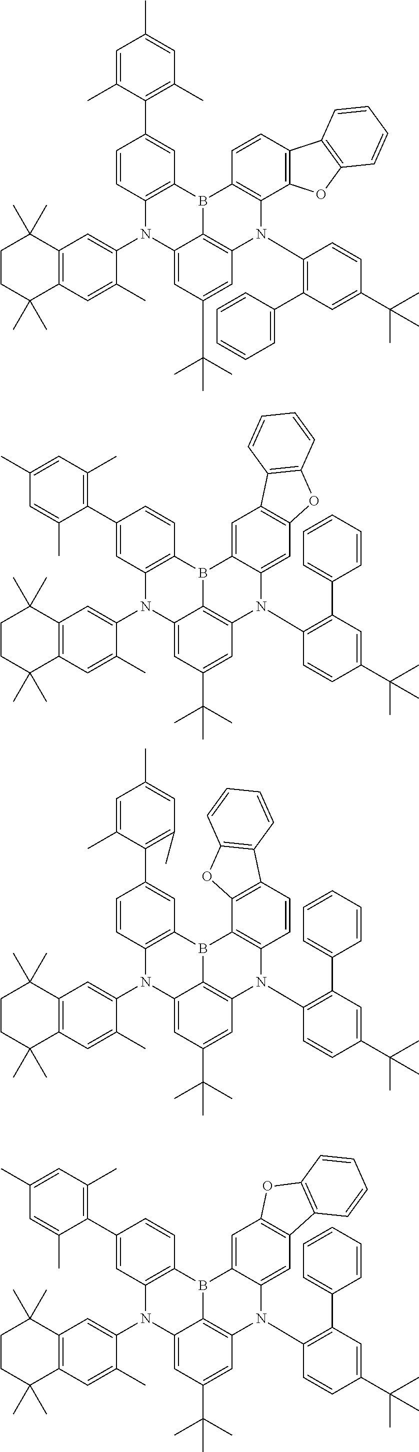

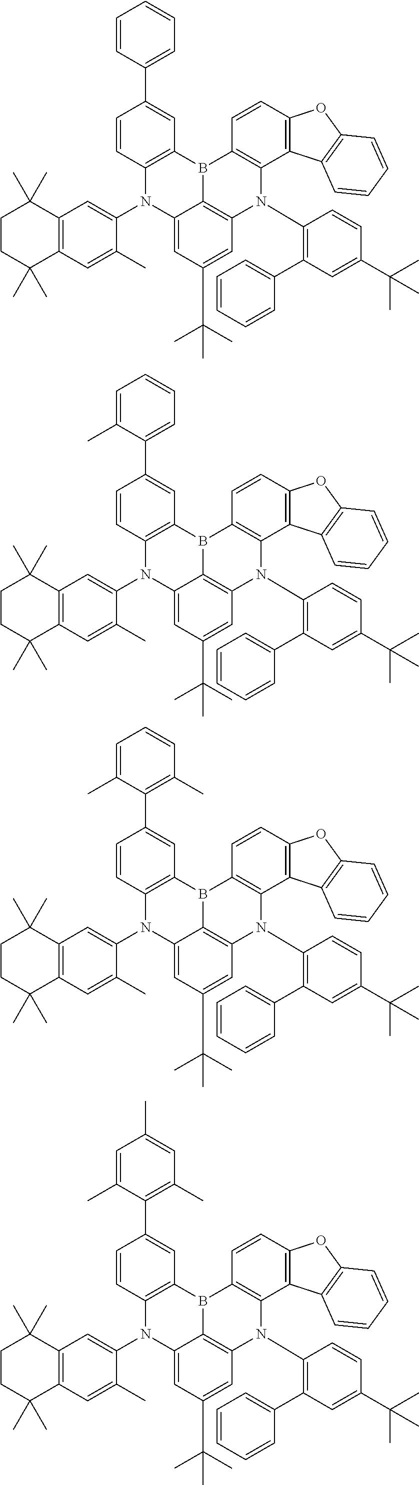

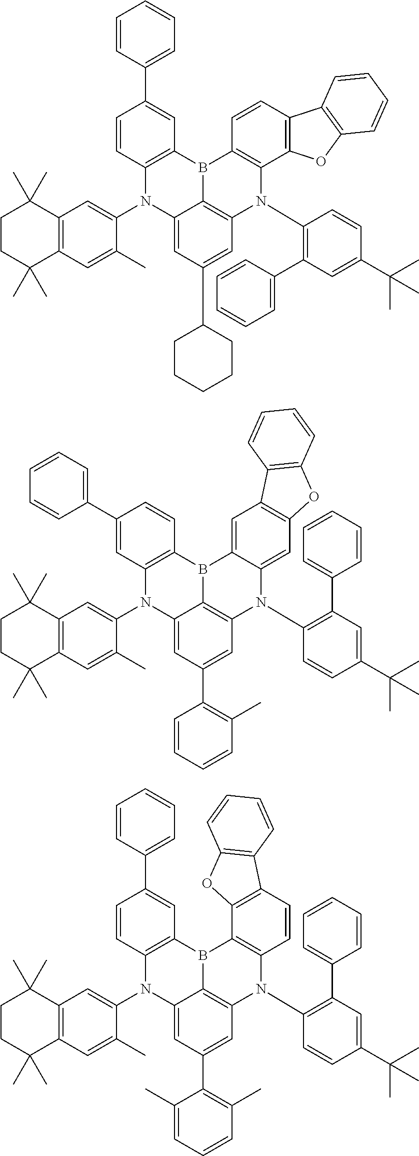

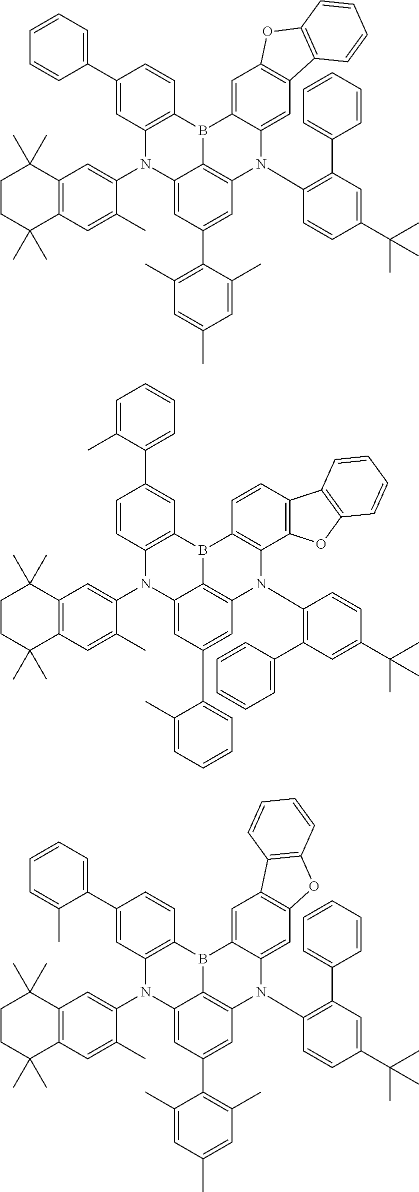

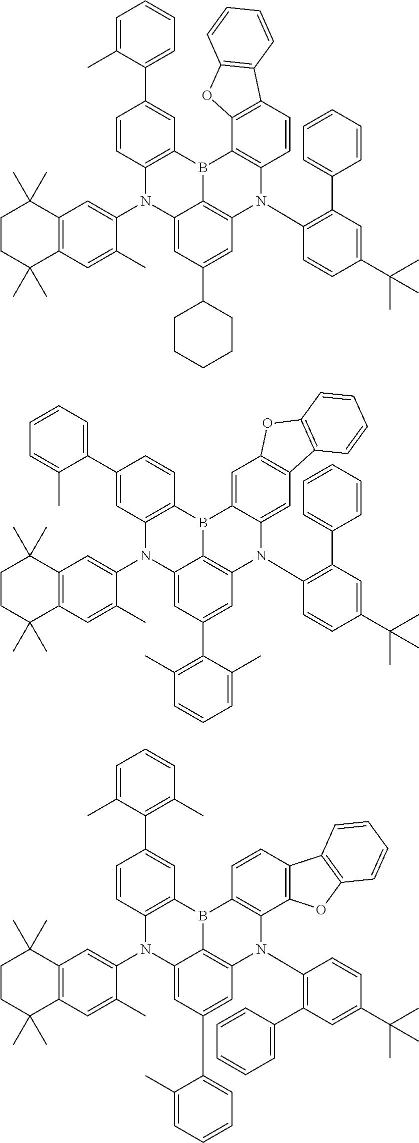 [SMILES: Cc1ccccc1-c1ccc2c(c1)B1c3c(cc(C4CCCCC4)cc3N(c3ccc(C(C)(C)C)cc3-c3ccccc3)c3ccc4c(oc5ccccc54)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(-c3c(C)cccc3C)cc3c1B2c1cc2oc4ccccc4c2cc1N3c1ccc(C(C)(C)C)cc1-c1ccccc1 ; Cc1ccccc1-c1cc2c3c(c1)N(c1ccc(C(C)(C)C)cc1-c1ccccc1)c1c(ccc4c1oc1ccccc14)B3c1cc(-c3c(C)cccc3C)ccc1N2c1cc2c(cc1C)C(C)(C)CCC2(C)C]

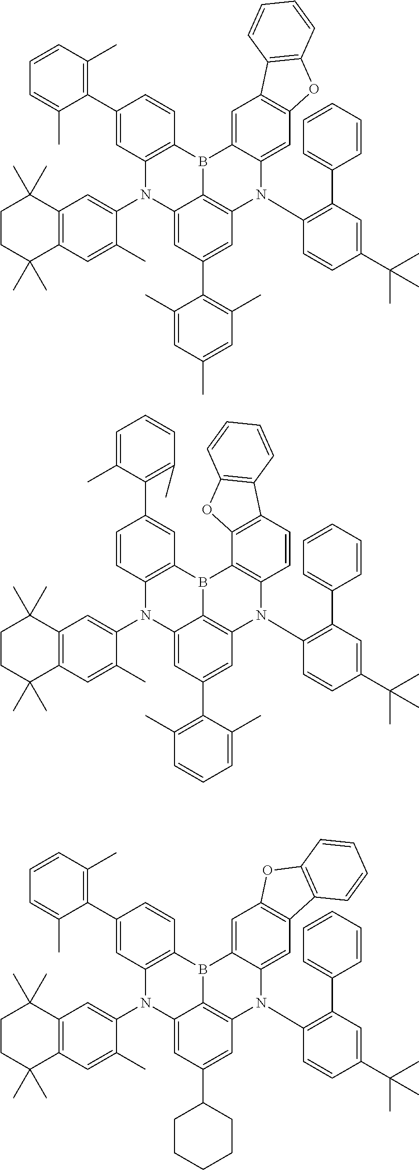

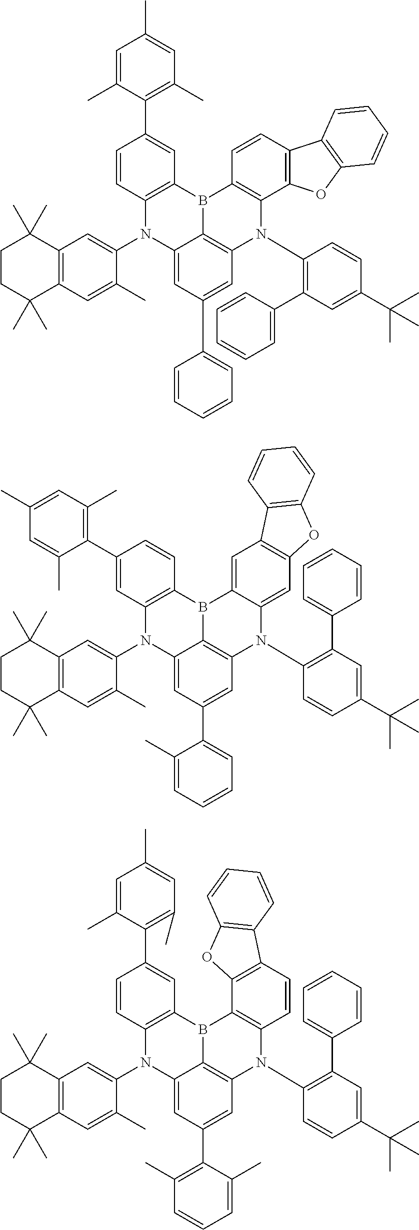 [SMILES: Cc1cc(C)c(-c2ccc3c(c2)B2c4ccc5c(oc6ccccc65)c4N(c4ccc(C(C)(C)C)cc4-c4ccccc4)c4cc(-c5ccccc5)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(-c4ccccc4C)cc4c2B3c2cc3c(cc2N4c2ccc(C(C)(C)C)cc2-c2ccccc2)oc2ccccc23)c(C)c1 ; Cc1cc(C)c(-c2ccc3c(c2)B2c4c(cc(-c5c(C)cccc5C)cc4N(c4ccc(C(C)(C)C)cc4-c4ccccc4)c4ccc5c(oc6ccccc65)c42)N3c2cc3c(cc2C)C(C)(C)CCC3(C)C)c(C)c1]

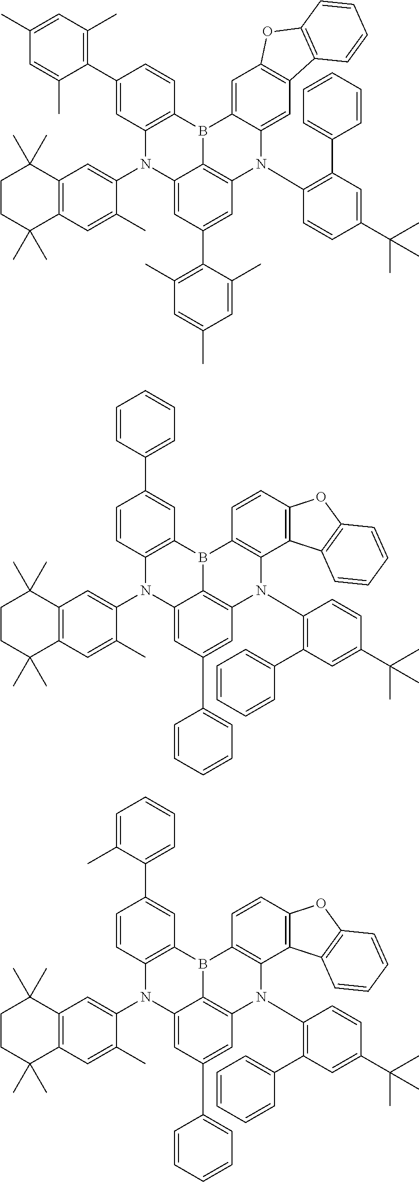 [SMILES: Cc1cc(C)c(-c2ccc3c(c2)N(c2cc4c(cc2C)C(C)(C)CCC4(C)C)c2cc(-c4c(C)cc(C)cc4C)cc4c2B3c2cc3oc5ccccc5c3cc2N4c2ccc(C(C)(C)C)cc2-c2ccccc2)c(C)c1 ; Cc1cc2c(cc1N1c3ccc(-c4ccccc4)cc3B3c4ccc5oc6ccccc6c5c4N(c4ccc(C(C)(C)C)cc4-c4ccccc4)c4cc(-c5ccccc5)cc1c43)C(C)(C)CCC2(C)C ; Cc1ccccc1-c1ccc2c(c1)B1c3ccc4oc5ccccc5c4c3N(c3ccc(C(C)(C)C)cc3-c3ccccc3)c3cc(-c4ccccc4)cc(c31)N2c1cc2c(cc1C)C(C)(C)CCC2(C)C]

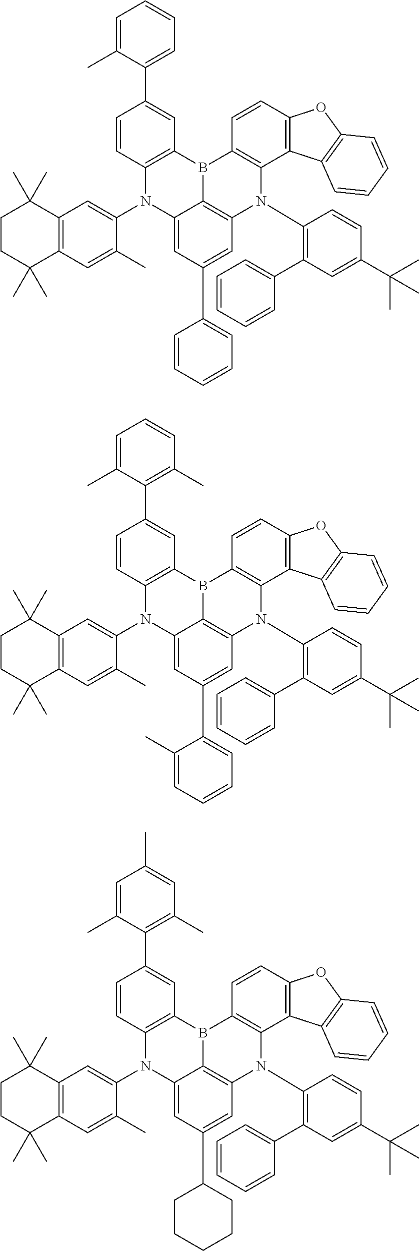 [SMILES: Cc1ccccc1-c1ccc2c(c1)B1c3ccc4oc5ccccc5c4c3N(c3ccc(C(C)(C)C)cc3-c3ccccc3)c3cc(-c4ccccc4)cc(c31)N2c1cc2c(cc1C)C(C)(C)CCC2(C)C ; Cc1ccccc1-c1cc2c3c(c1)N(c1ccc(C(C)(C)C)cc1-c1ccccc1)c1c(ccc4oc5ccccc5c14)B3c1cc(-c3c(C)cccc3C)ccc1N2c1cc2c(cc1C)C(C)(C)CCC2(C)C ; Cc1cc(C)c(-c2ccc3c(c2)B2c4ccc5oc6ccccc6c5c4N(c4ccc(C(C)(C)C)cc4-c4ccccc4)c4cc(C5CCCCC5)cc(c42)N3c2cc3c(cc2C)C(C)(C)CCC3(C)C)c(C)c1]

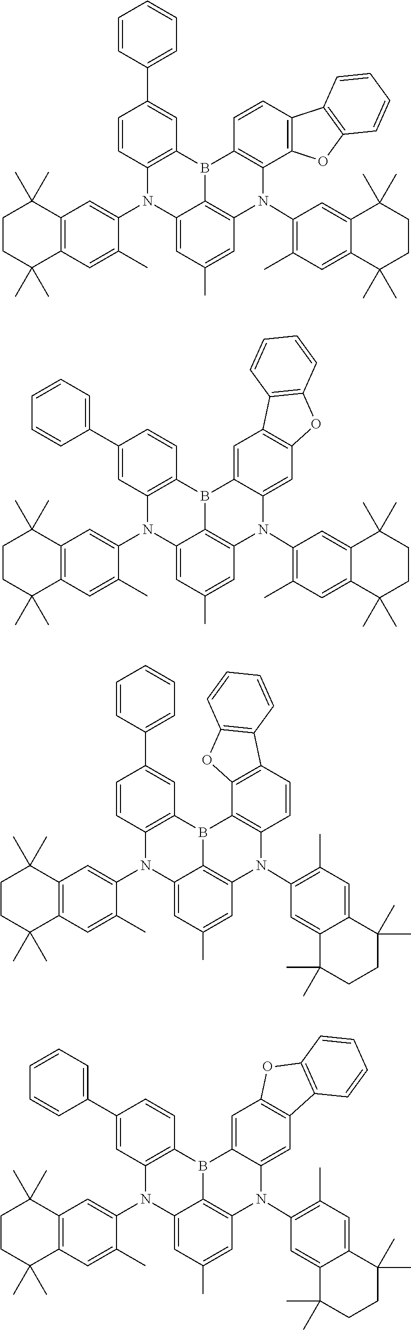

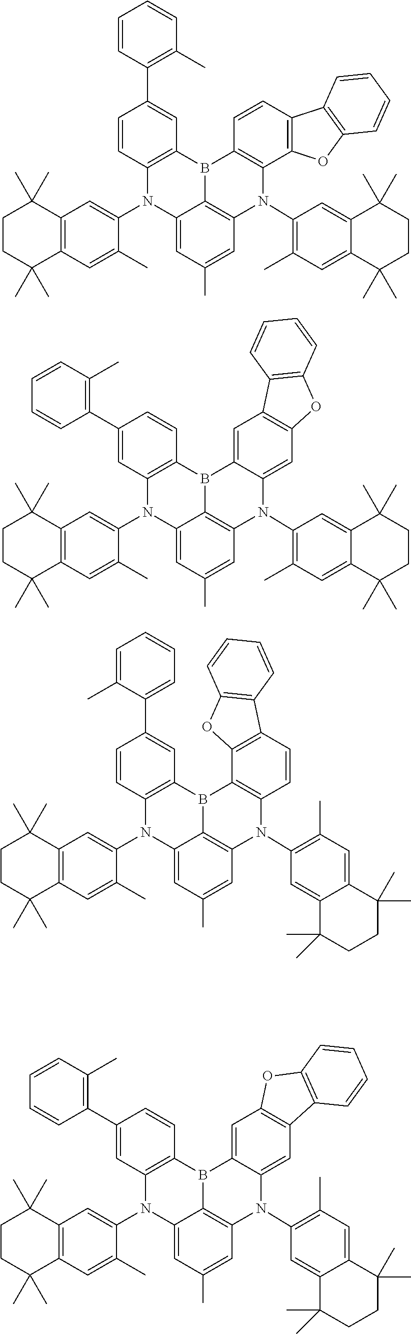

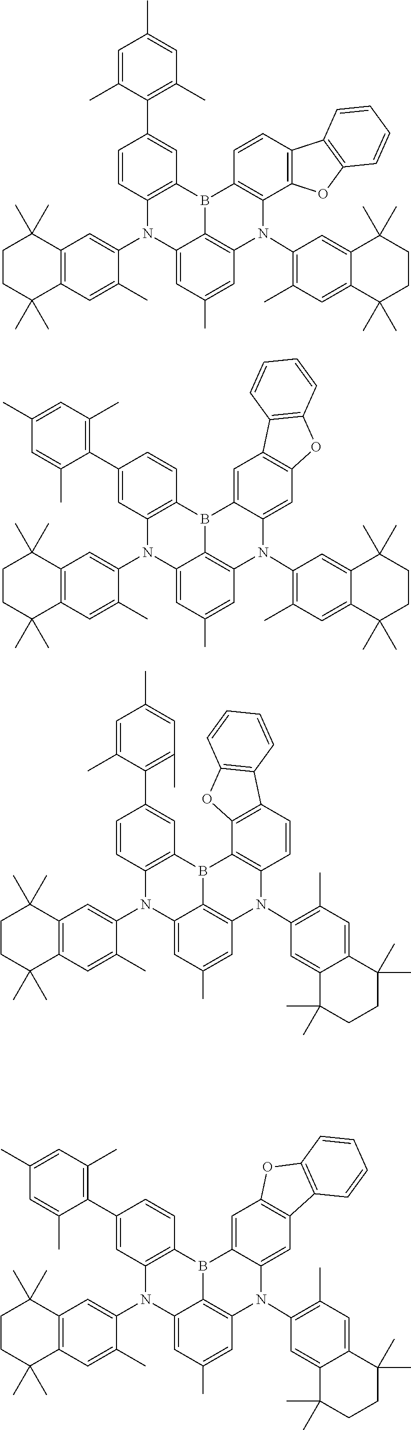

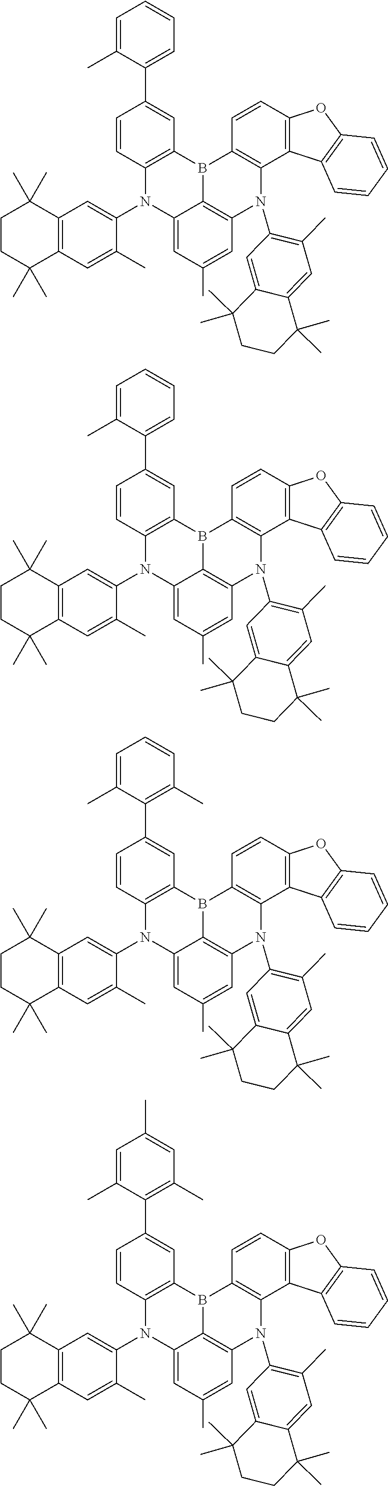 [SMILES: Cc1cc2c3c(c1)N(c1cc4c(cc1C)C(C)(C)CCC4(C)C)c1c(ccc4oc5ccccc5c14)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1c(ccc4oc5ccccc5c14)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1c(ccc4oc5ccccc5c14)B3c1cc(-c3c(C)cccc3C)ccc1N2c1cc2c(cc1C)C(C)(C)CCC2(C)C ; Cc1cc(C)c(-c2ccc3c(c2)B2c4ccc5oc6ccccc6c5c4N(c4cc5c(cc4C)C(C)(C)CCC5(C)C)c4cc(C)cc(c42)N3c2cc3c(cc2C)C(C)(C)CCC3(C)C)c(C)c1]

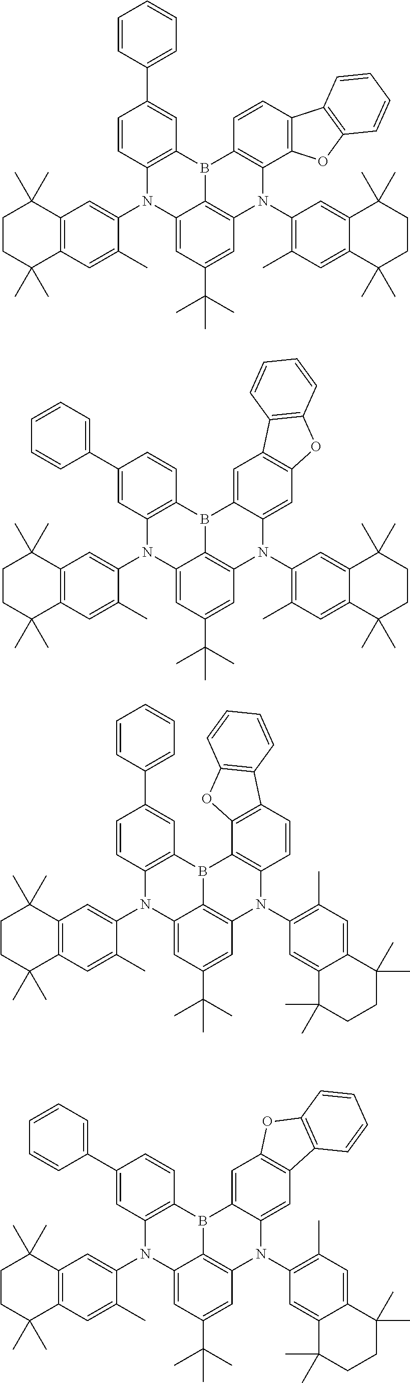

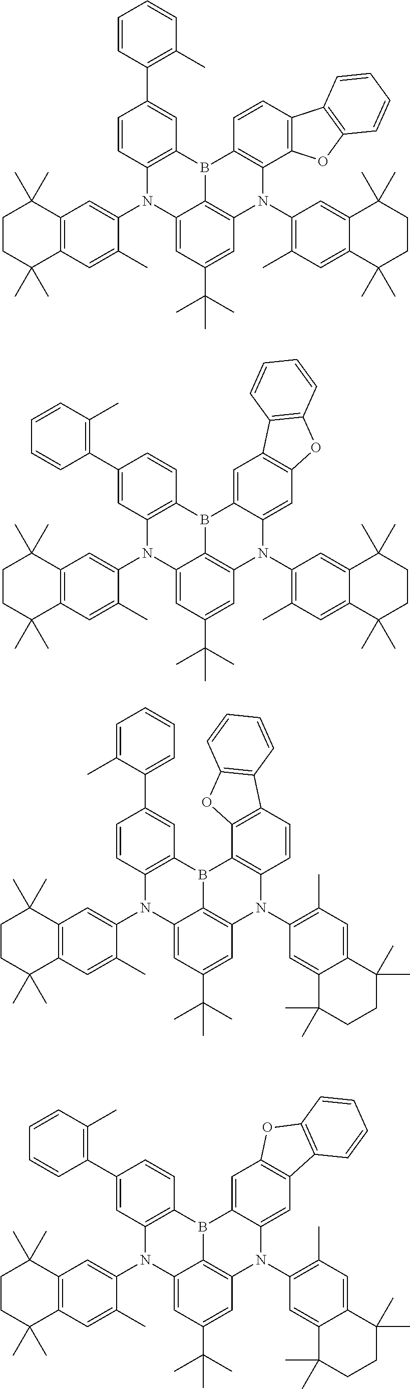

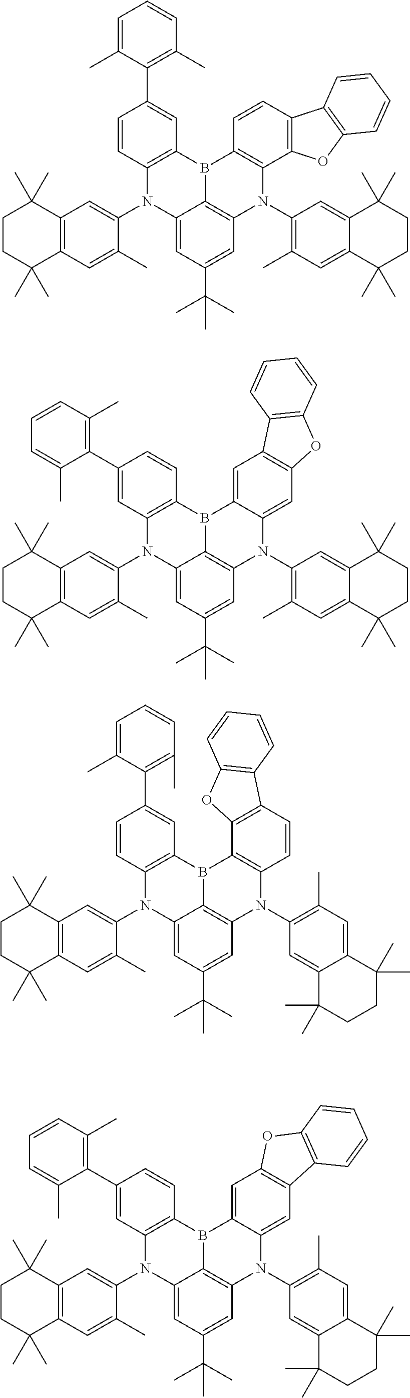

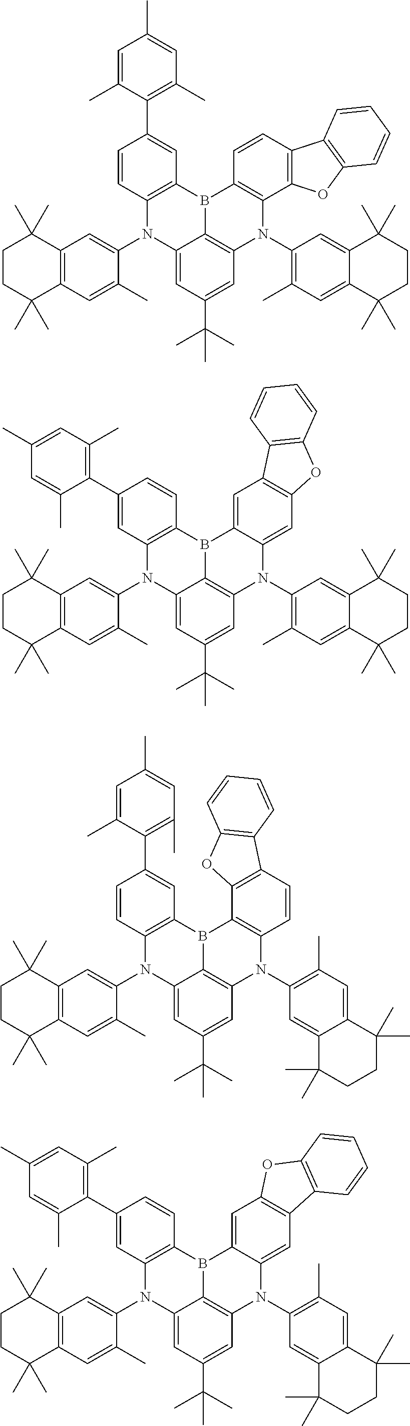

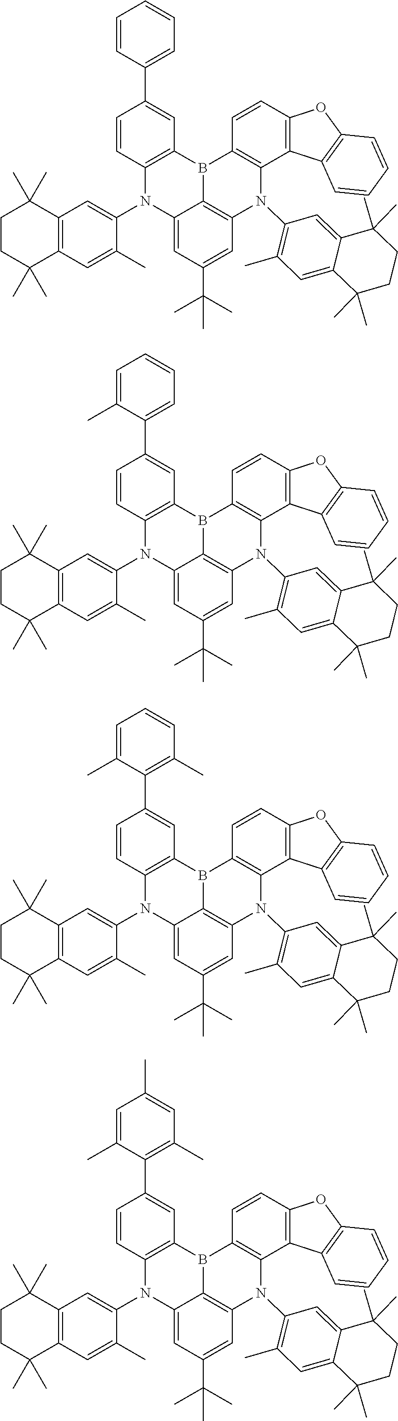

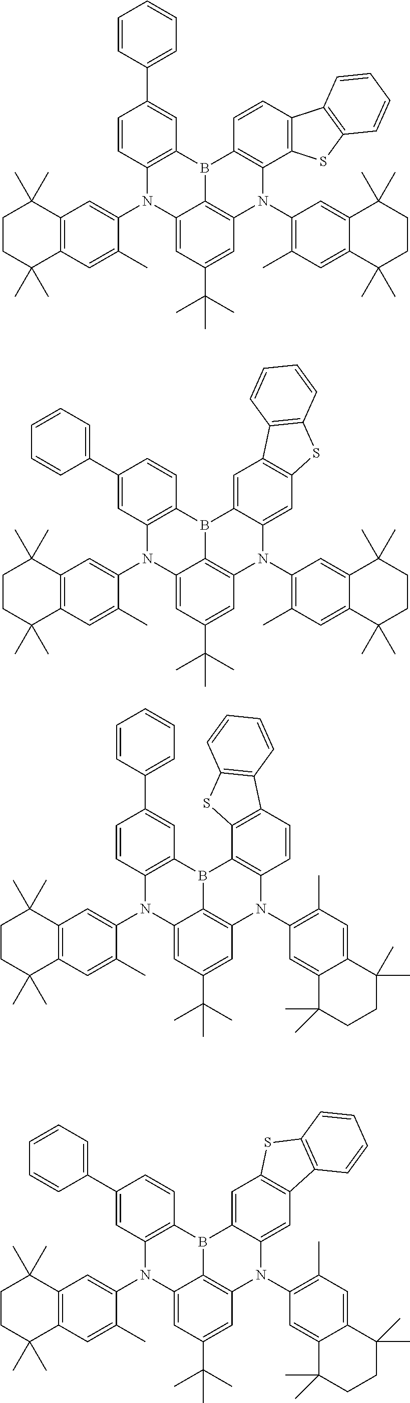

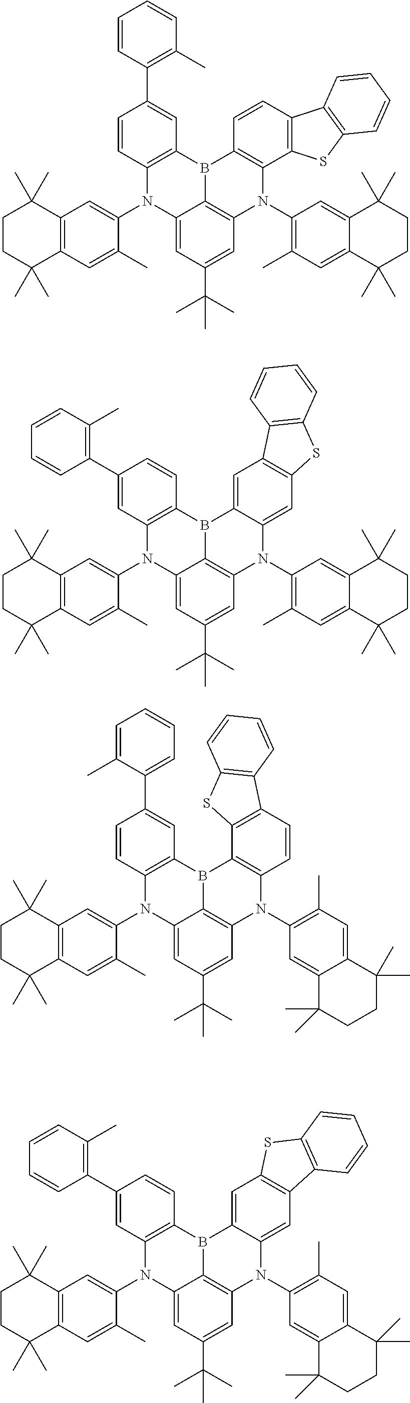

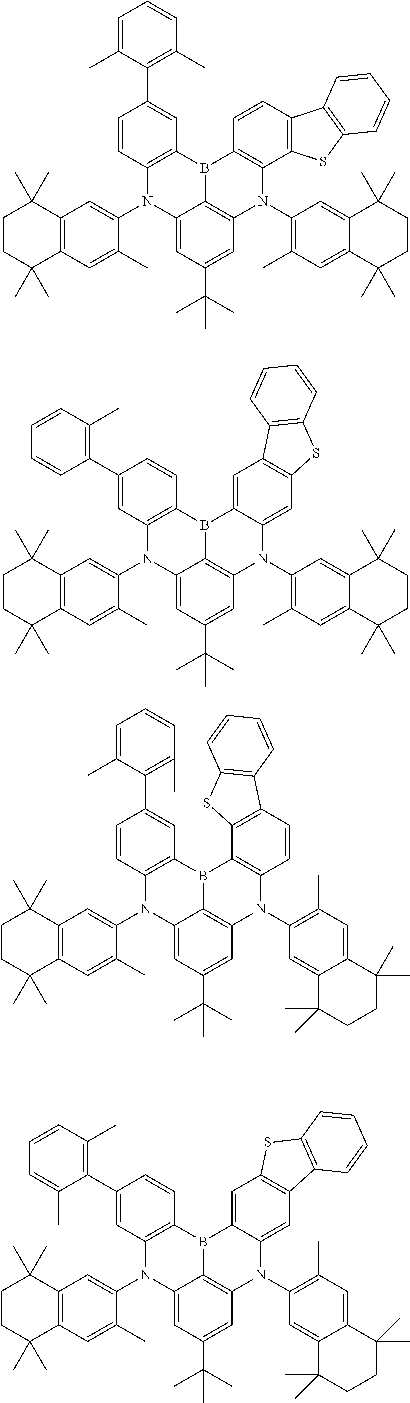

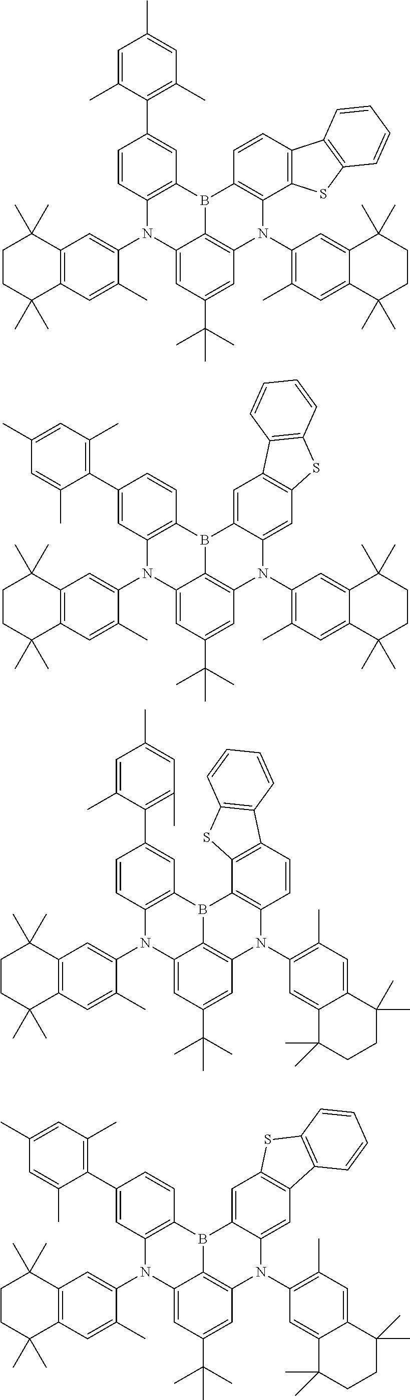

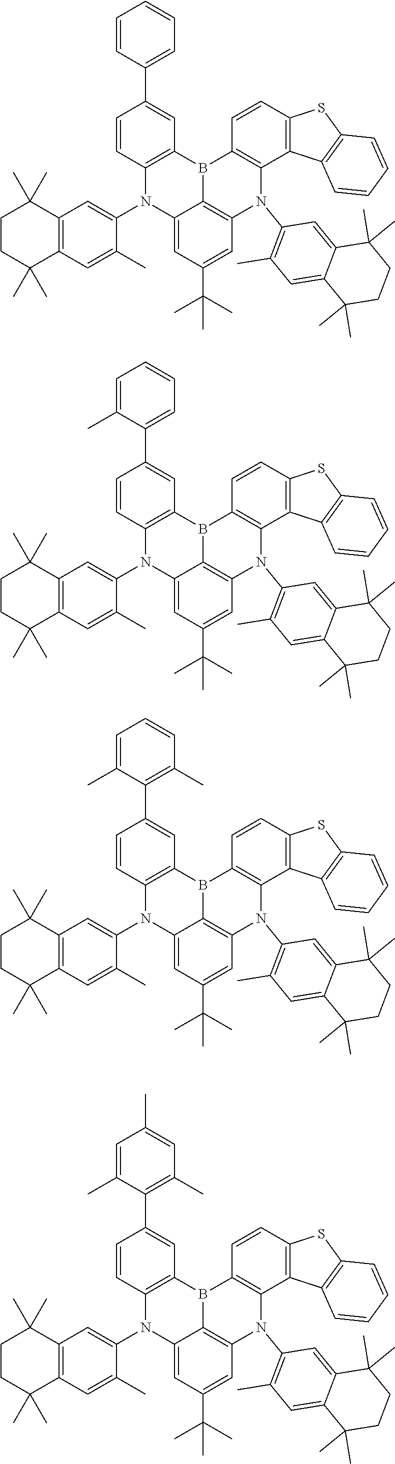

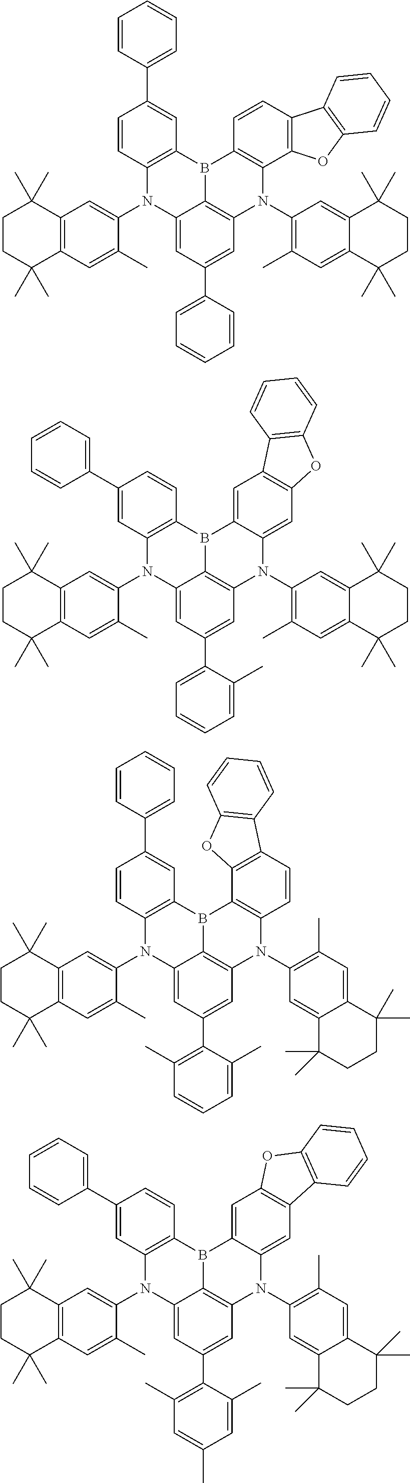

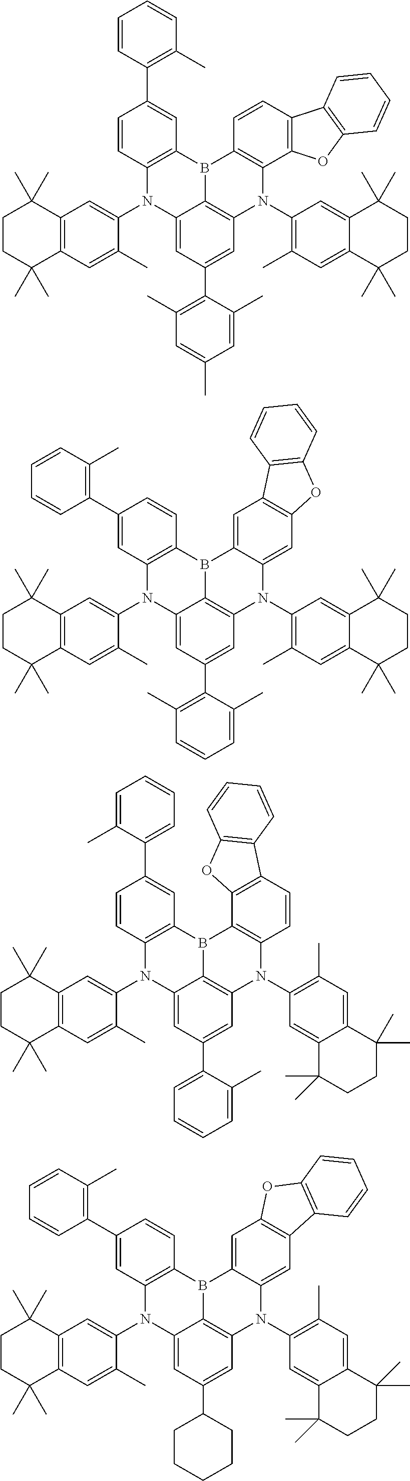

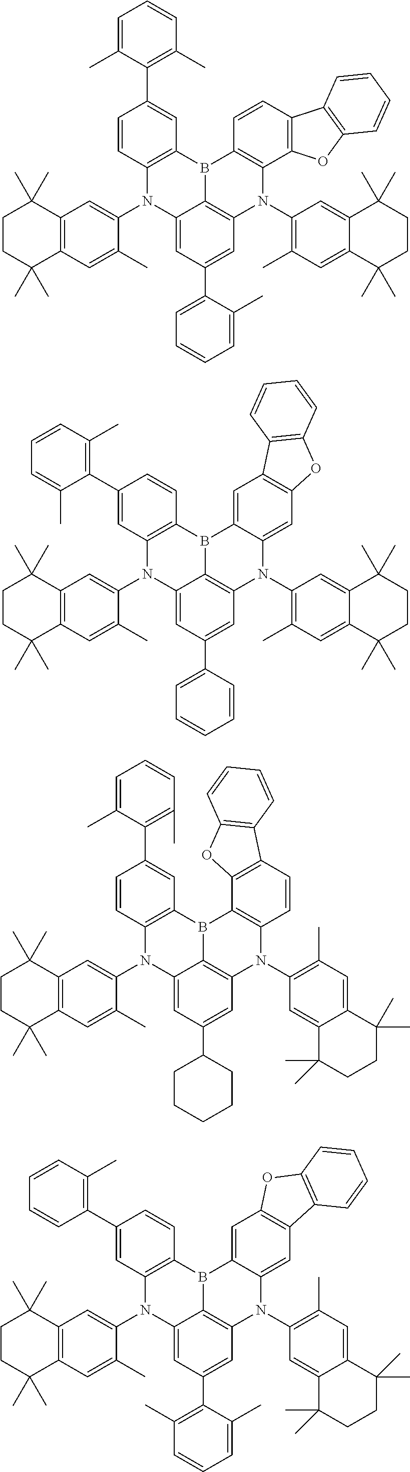

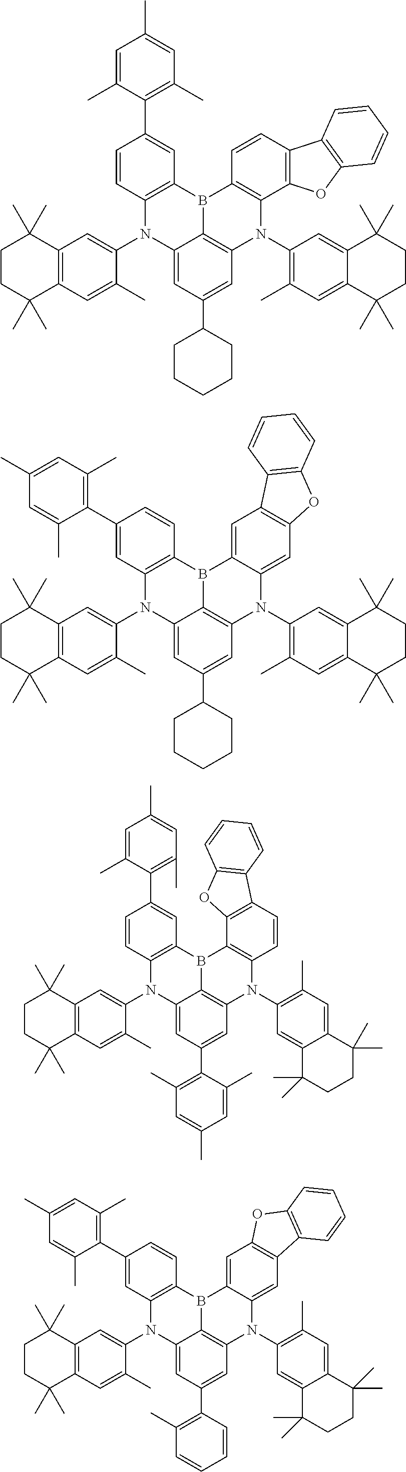

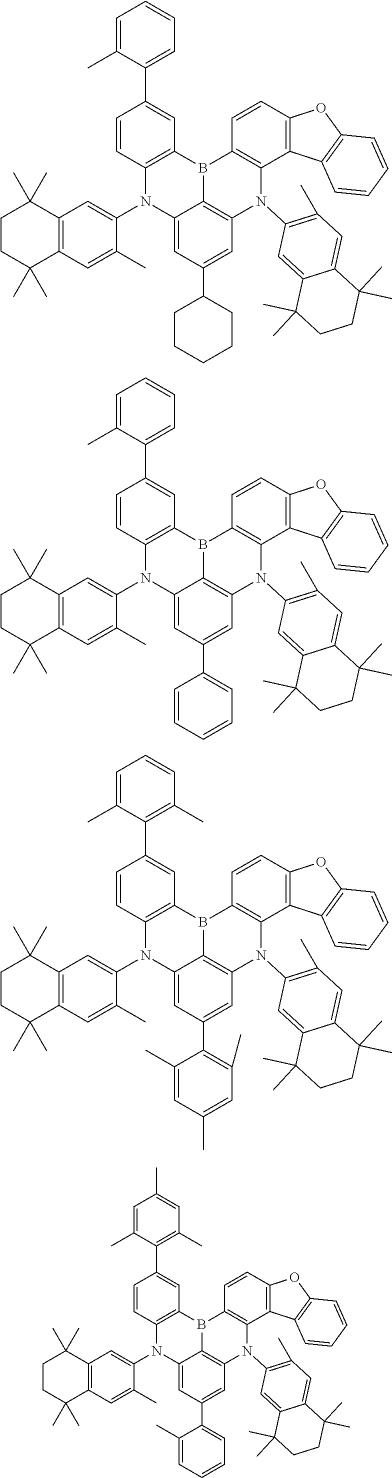

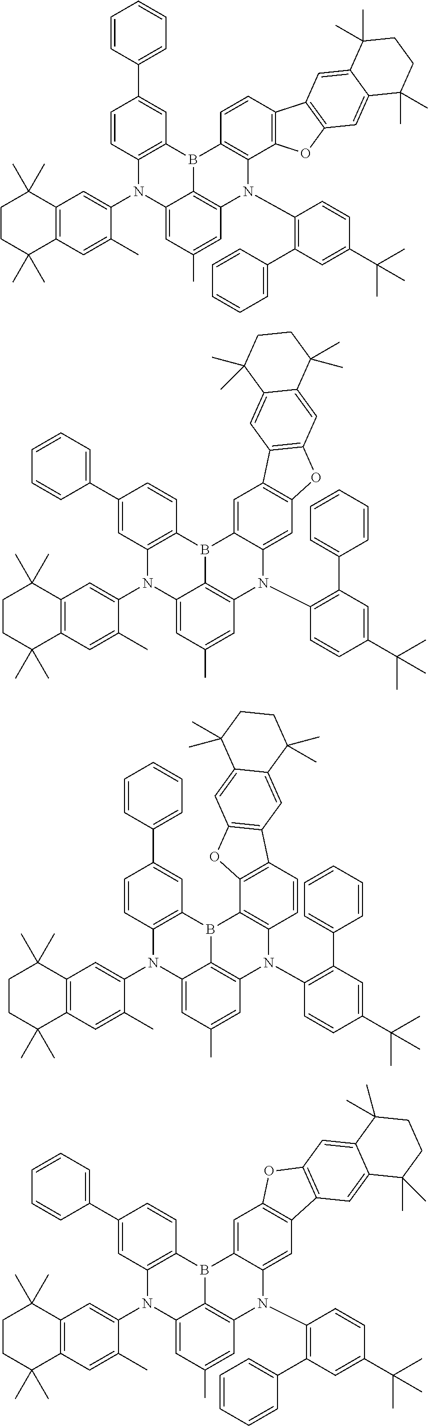

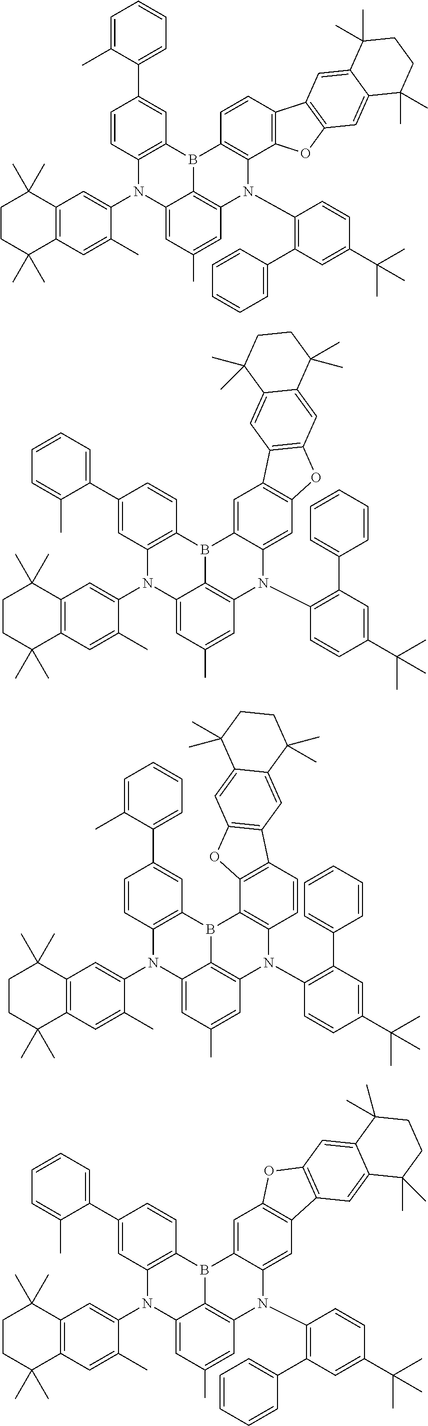

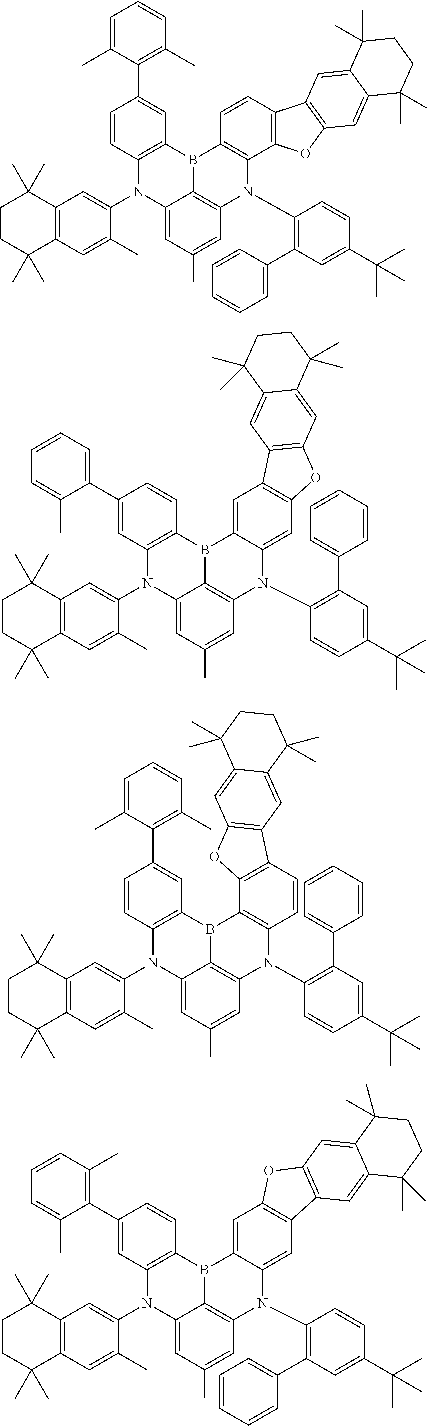

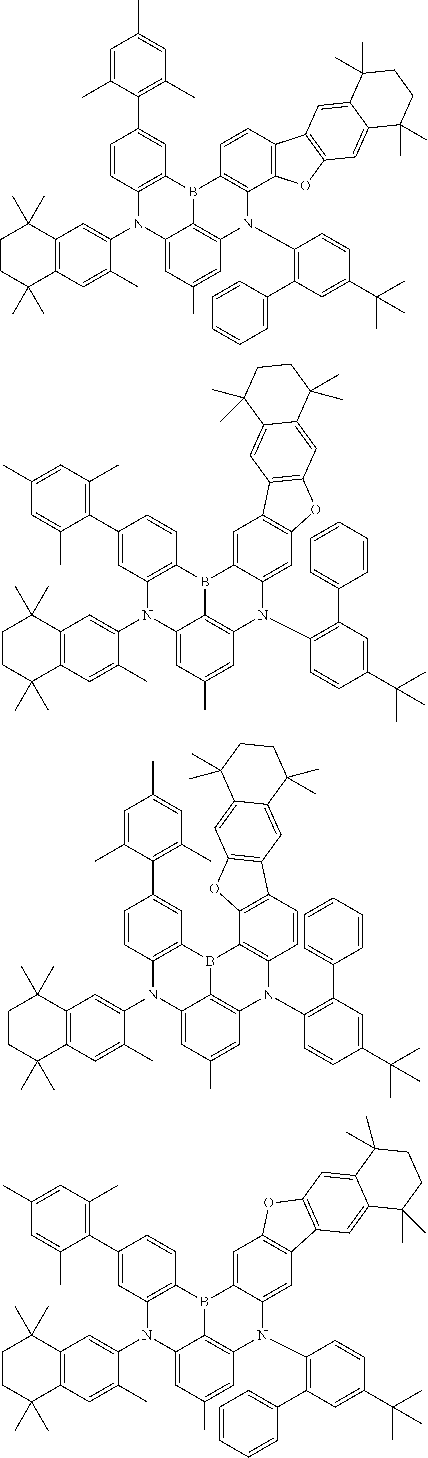

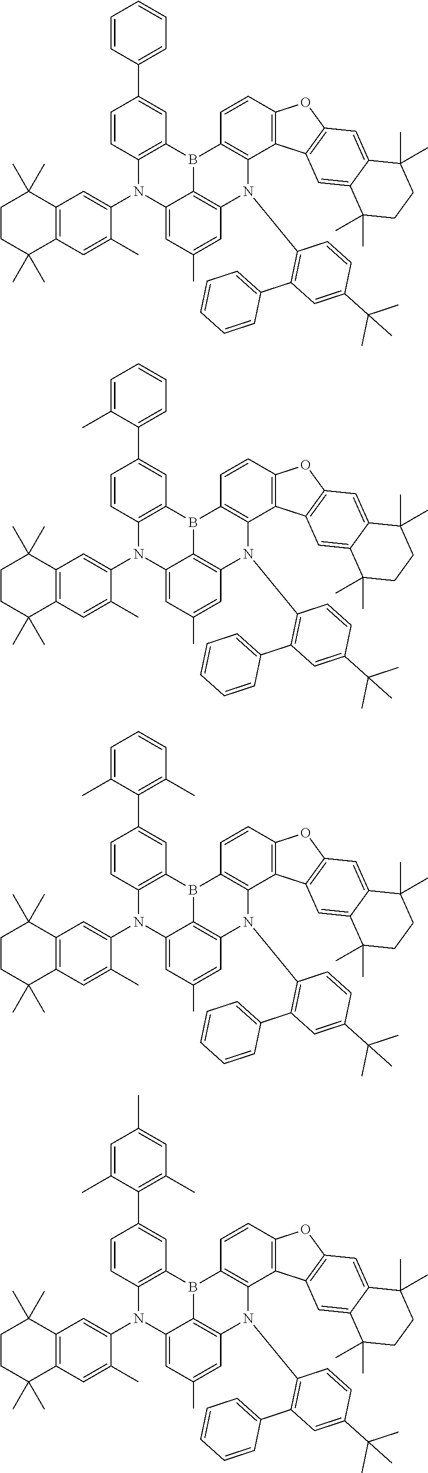

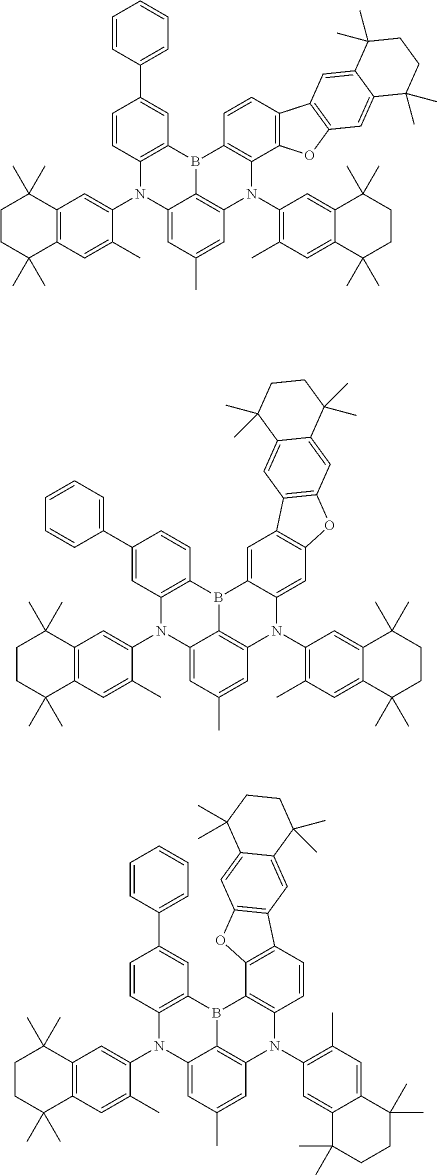 [SMILES: Cc1cc2c3c(c1)N(c1cc4c(cc1C)C(C)(C)CCC4(C)C)c1c(ccc4c1oc1cc5c(cc14)C(C)(C)CCC5(C)C)B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4oc5cc6c(cc5c4cc1B3c1ccc(-c3ccccc3)cc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(oc5cc6c(cc54)C(C)(C)CCC6(C)C)c1B3c1cc(-c3ccccc3)ccc1N2c1cc2c(cc1C)C(C)(C)CCC2(C)C]

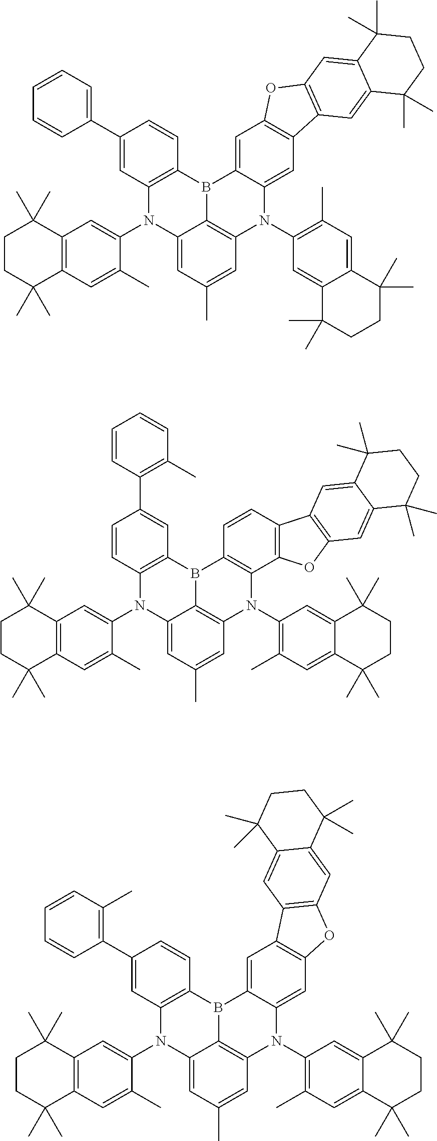 [SMILES: Cc1cc2c3c(c1)N(c1cc4c(cc1C)C(C)(C)CCC4(C)C)c1cc4c(cc1B3c1ccc(-c3ccccc3)cc1N2c1cc2c(cc1C)C(C)(C)CCC2(C)C)oc1cc2c(cc14)C(C)(C)CCC2(C)C ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4oc5cc6c(cc5c4cc1B3c1ccc(-c3ccccc3C)cc1N2c1cc2c(cc1C)C(C)(C)CCC2(C)C)C(C)(C)CCC6(C)C]

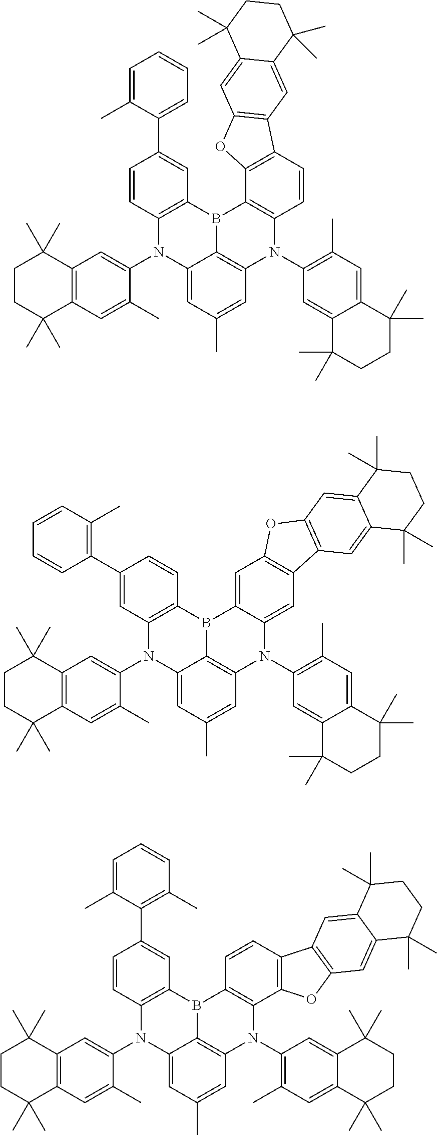 [SMILES: Cc1cc2c3c(c1)N(c1cc4c(cc1C)C(C)(C)CCC4(C)C)c1ccc4c(oc5cc6c(cc54)C(C)(C)CCC6(C)C)c1B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3ccccc3C)cc1N2c1cc2c(cc1C)C(C)(C)CCC2(C)C)oc1cc2c(cc14)C(C)(C)CCC2(C)C ; Cc1cc2c3c(c1)N(c1cc4c(cc1C)C(C)(C)CCC4(C)C)c1c(ccc4c1oc1cc5c(cc14)C(C)(C)CCC5(C)C)B3c1cc(-c3c(C)cccc3C)ccc1N2c1cc2c(cc1C)C(C)(C)CCC2(C)C]

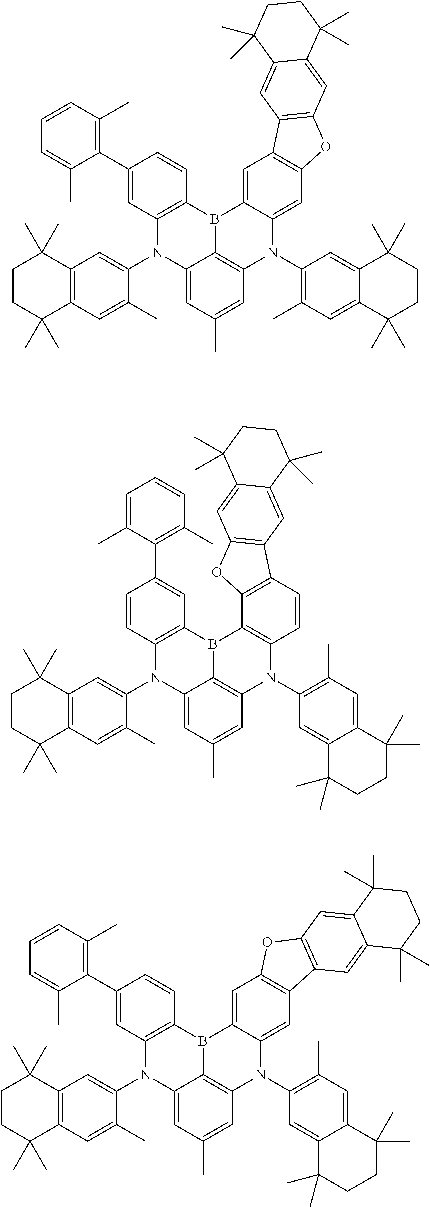 [SMILES: Cc1cc2c3c(c1)N(c1cc4c(cc1C)C(C)(C)CCC4(C)C)c1cc4oc5cc6c(cc5c4cc1B3c1ccc(-c3c(C)cccc3C)cc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(oc5cc6c(cc54)C(C)(C)CCC6(C)C)c1B3c1cc(-c3c(C)cccc3C)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3c(C)cccc3C)cc1N2c1cc2c(cc1C)C(C)(C)CCC2(C)C)oc1cc2c(cc14)C(C)(C)CCC2(C)C]

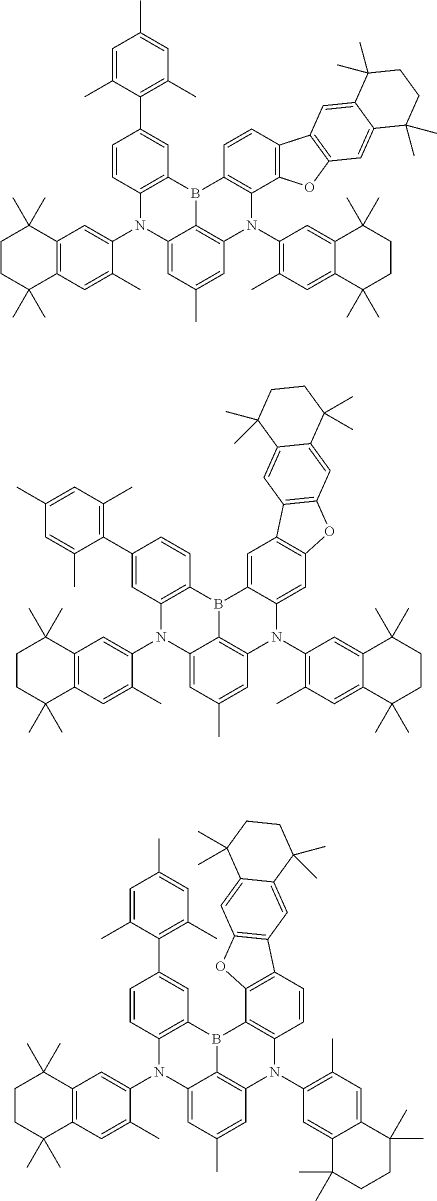 [SMILES: Cc1cc(C)c(-c2ccc3c(c2)B2c4ccc5c(oc6cc7c(cc65)C(C)(C)CCC7(C)C)c4N(c4cc5c(cc4C)C(C)(C)CCC5(C)C)c4cc(C)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(C)cc4c2B3c2cc3c(cc2N4c2cc4c(cc2C)C(C)(C)CCC4(C)C)oc2cc4c(cc23)C(C)(C)CCC4(C)C)c(C)c1 ; Cc1cc(C)c(-c2ccc3c(c2)B2c4c(cc(C)cc4N(c4cc5c(cc4C)C(C)(C)CCC5(C)C)c4ccc5c(oc6cc7c(cc65)C(C)(C)CCC7(C)C)c42)N3c2cc3c(cc2C)C(C)(C)CCC3(C)C)c(C)c1]

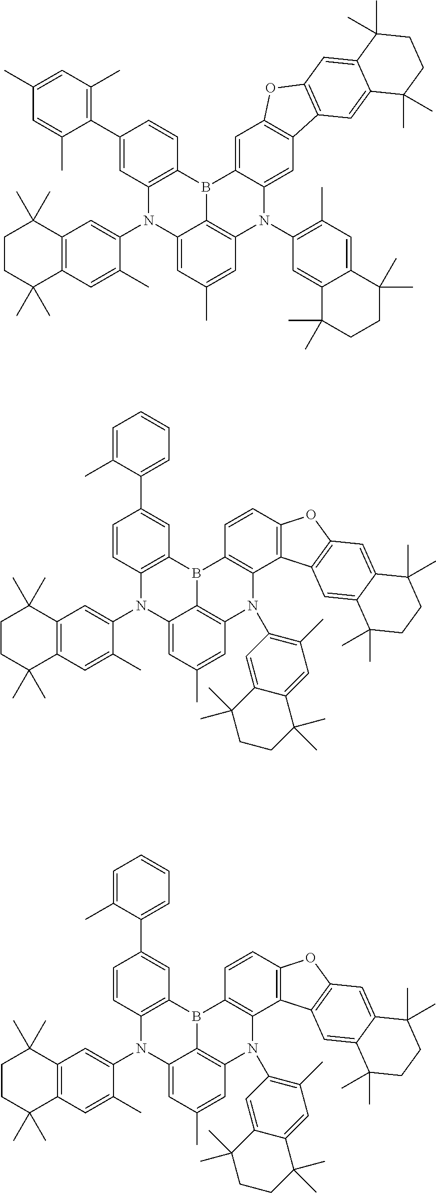 [SMILES: Cc1cc(C)c(-c2ccc3c(c2)N(c2cc4c(cc2C)C(C)(C)CCC4(C)C)c2cc(C)cc4c2B3c2cc3oc5cc6c(cc5c3cc2N4c2cc3c(cc2C)C(C)(C)CCC3(C)C)C(C)(C)CCC6(C)C)c(C)c1 ; Cc1cc2c3c(c1)N(c1cc4c(cc1C)C(C)(C)CCC4(C)C)c1c(ccc4oc5cc6c(cc5c14)C(C)(C)CCC6(C)C)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1c(ccc4oc5cc6c(cc5c14)C(C)(C)CCC6(C)C)B3c1cc(-c3ccccc3C)ccc1N2c1cc2c(cc1C)C(C)(C)CCC2(C)C]

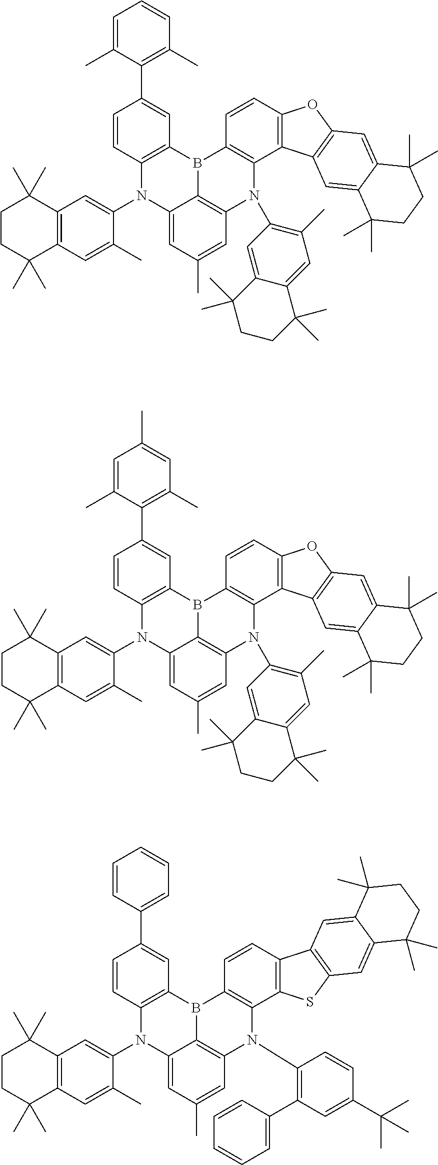 [SMILES: Cc1cc2c3c(c1)N(c1cc4c(cc1C)C(C)(C)CCC4(C)C)c1c(ccc4oc5cc6c(cc5c14)C(C)(C)CCC6(C)C)B3c1cc(-c3c(C)cccc3C)ccc1N2c1cc2c(cc1C)C(C)(C)CCC2(C)C ; Cc1cc(C)c(-c2ccc3c(c2)B2c4ccc5oc6cc7c(cc6c5c4N(c4cc5c(cc4C)C(C)(C)CCC5(C)C)c4cc(C)cc(c42)N3c2cc3c(cc2C)C(C)(C)CCC3(C)C)C(C)(C)CCC7(C)C)c(C)c1 ; Cc1cc2c3c(c1)N(c1ccc(C(C)(C)C)cc1-c1ccccc1)c1c(ccc4c1sc1cc5c(cc14)C(C)(C)CCC5(C)C)B3c1cc(-c3ccccc3)ccc1N2c1cc2c(cc1C)C(C)(C)CCC2(C)C]

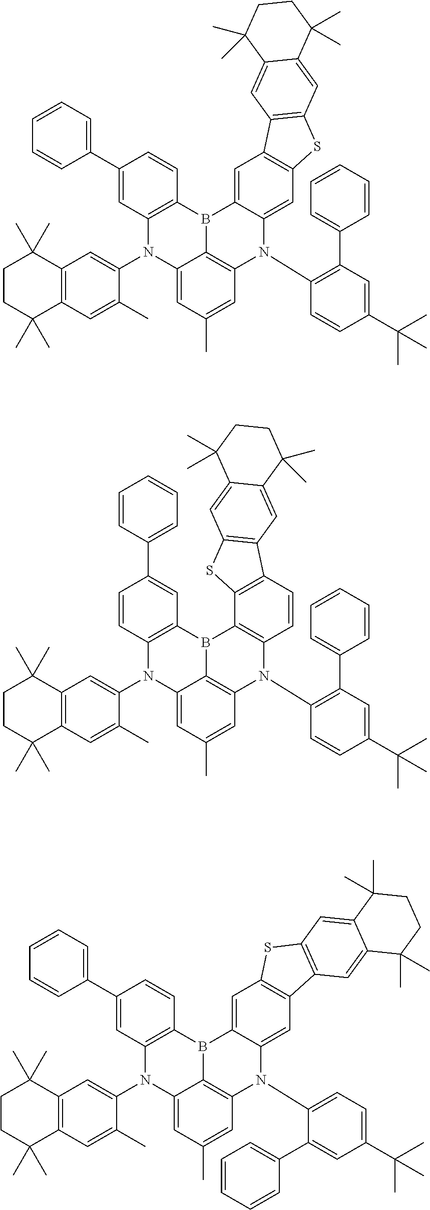 [SMILES: Cc1cc2c3c(c1)N(c1ccc(C(C)(C)C)cc1-c1ccccc1)c1cc4sc5cc6c(cc5c4cc1B3c1ccc(-c3ccccc3)cc1N2c1cc2c(cc1C)C(C)(C)CCC2(C)C)C(C)(C)CCC6(C)C ; Cc1cc2c3c(c1)N(c1ccc(C(C)(C)C)cc1-c1ccccc1)c1ccc4c(sc5cc6c(cc54)C(C)(C)CCC6(C)C)c1B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3ccccc3)cc1N2c1cc2c(cc1C)C(C)(C)CCC2(C)C)sc1cc2c(cc14)C(C)(C)CCC2(C)C]

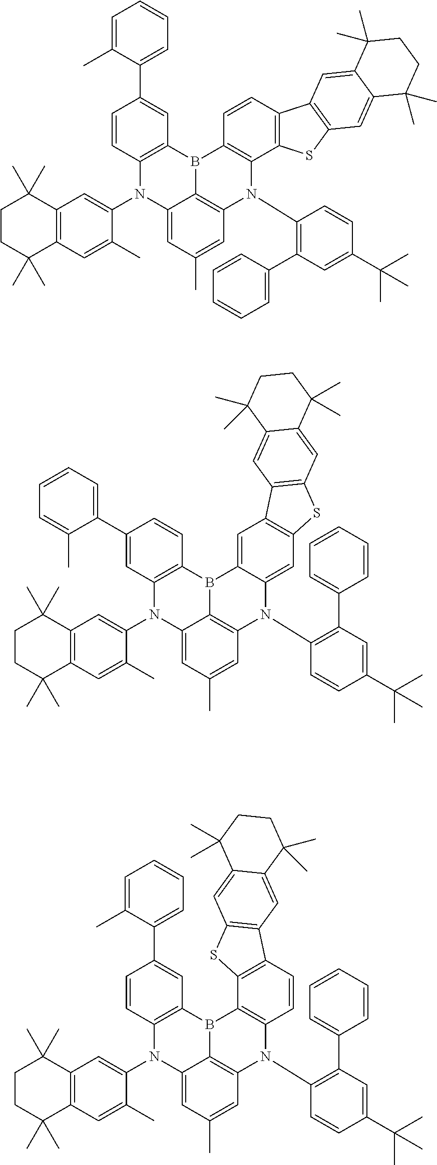 [SMILES: Cc1cc2c3c(c1)N(c1ccc(C(C)(C)C)cc1-c1ccccc1)c1c(ccc4c1sc1cc5c(cc14)C(C)(C)CCC5(C)C)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1cc4sc5cc6c(cc5c4cc1B3c1ccc(-c3ccccc3C)cc1N2c1cc2c(cc1C)C(C)(C)CCC2(C)C)C(C)(C)CCC6(C)C ; Cc1cc2c3c(c1)N(c1ccc(C(C)(C)C)cc1-c1ccccc1)c1ccc4c(sc5cc6c(cc54)C(C)(C)CCC6(C)C)c1B3c1cc(-c3ccccc3C)ccc1N2c1cc2c(cc1C)C(C)(C)CCC2(C)C]

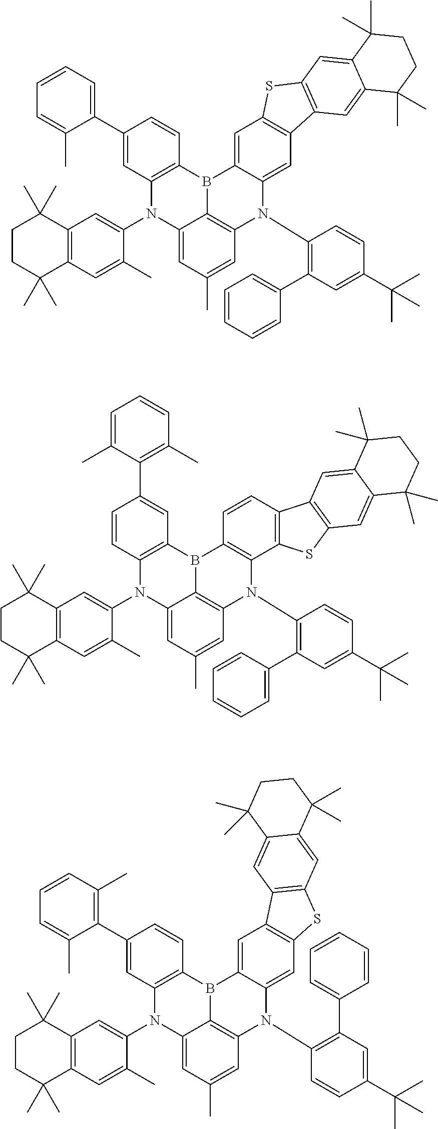 [SMILES: Cc1cc2c3c(c1)N(c1ccc(C(C)(C)C)cc1-c1ccccc1)c1cc4c(cc1B3c1ccc(-c3ccccc3C)cc1N2c1cc2c(cc1C)C(C)(C)CCC2(C)C)sc1cc2c(cc14)C(C)(C)CCC2(C)C ; Cc1cc2c3c(c1)N(c1ccc(C(C)(C)C)cc1-c1ccccc1)c1c(ccc4c1sc1cc5c(cc14)C(C)(C)CCC5(C)C)B3c1cc(-c3c(C)cccc3C)ccc1N2c1cc2c(cc1C)C(C)(C)CCC2(C)C ; Cc1cc2c3c(c1)N(c1ccc(C(C)(C)C)cc1-c1ccccc1)c1cc4sc5cc6c(cc5c4cc1B3c1ccc(-c3c(C)cccc3C)cc1N2c1cc2c(cc1C)C(C)(C)CCC2(C)C)C(C)(C)CCC6(C)C]

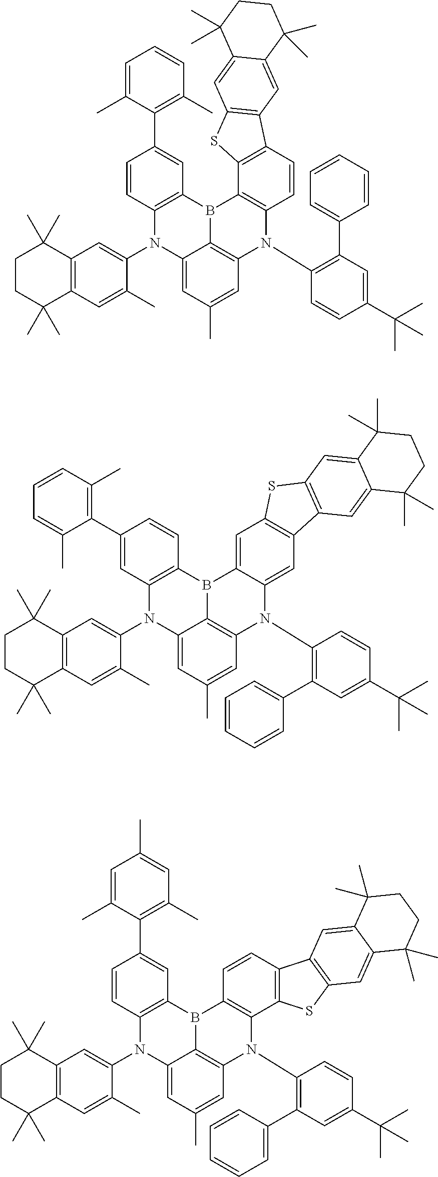 [SMILES: Cc1cc2c3c(c1)N(c1ccc(C(C)(C)C)cc1-c1ccccc1)c1ccc4c(sc5cc6c(cc54)C(C)(C)CCC6(C)C)c1B3c1cc(-c3c(C)cccc3C)ccc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(-c3c(C)cccc3C)cc1N2c1cc2c(cc1C)C(C)(C)CCC2(C)C)sc1cc2c(cc14)C(C)(C)CCC2(C)C ; Cc1cc(C)c(-c2ccc3c(c2)B2c4ccc5c(sc6cc7c(cc65)C(C)(C)CCC7(C)C)c4N(c4ccc(C(C)(C)C)cc4-c4ccccc4)c4cc(C)cc(c42)N3c2cc3c(cc2C)C(C)(C)CCC3(C)C)c(C)c1]

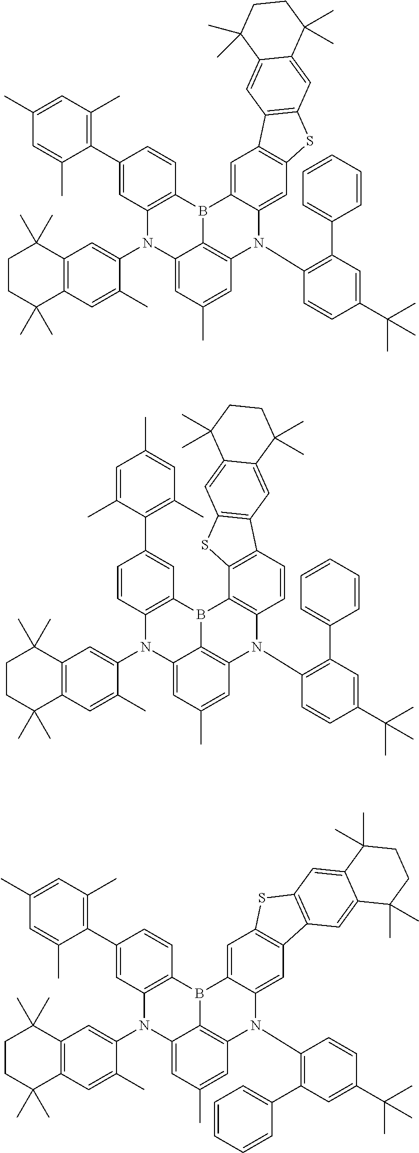

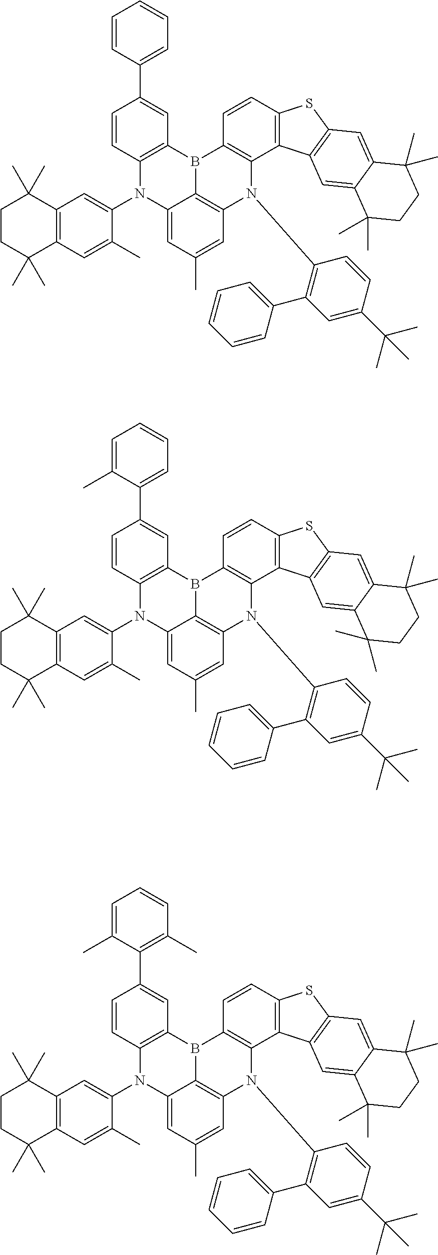 [SMILES: Cc1cc2c3c(c1)N(c1ccc(C(C)(C)C)cc1-c1ccccc1)c1c(ccc4sc5cc6c(cc5c14)C(C)(C)CCC6(C)C)B3c1cc(-c3ccccc3)ccc1N2c1cc2c(cc1C)C(C)(C)CCC2(C)C ; Cc1cc2c3c(c1)N(c1ccc(C(C)(C)C)cc1-c1ccccc1)c1c(ccc4sc5cc6c(cc5c14)C(C)(C)CCC6(C)C)B3c1cc(-c3ccccc3C)ccc1N2c1cc2c(cc1C)C(C)(C)CCC2(C)C ; Cc1cc2c3c(c1)N(c1ccc(C(C)(C)C)cc1-c1ccccc1)c1c(ccc4sc5cc6c(cc5c14)C(C)(C)CCC6(C)C)B3c1cc(-c3c(C)cccc3C)ccc1N2c1cc2c(cc1C)C(C)(C)CCC2(C)C]

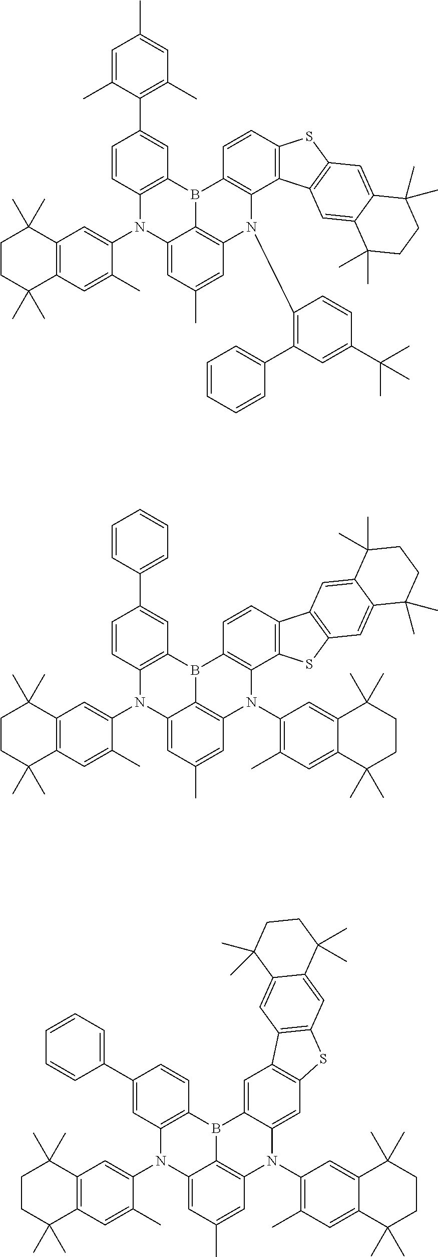 [SMILES: Cc1cc(C)c(-c2ccc3c(c2)B2c4ccc5sc6cc7c(cc6c5c4N(c4ccc(C(C)(C)C)cc4-c4ccccc4)c4cc(C)cc(c42)N3c2cc3c(cc2C)C(C)(C)CCC3(C)C)C(C)(C)CCC7(C)C)c(C)c1 ; Cc1cc2c3c(c1)N(c1cc4c(cc1C)C(C)(C)CCC4(C)C)c1c(ccc4c1sc1cc5c(cc14)C(C)(C)CCC5(C)C)B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4sc5cc6c(cc5c4cc1B3c1ccc(-c3ccccc3)cc1N2c1cc2c(cc1C)C(C)(C)CCC2(C)C)C(C)(C)CCC6(C)C]

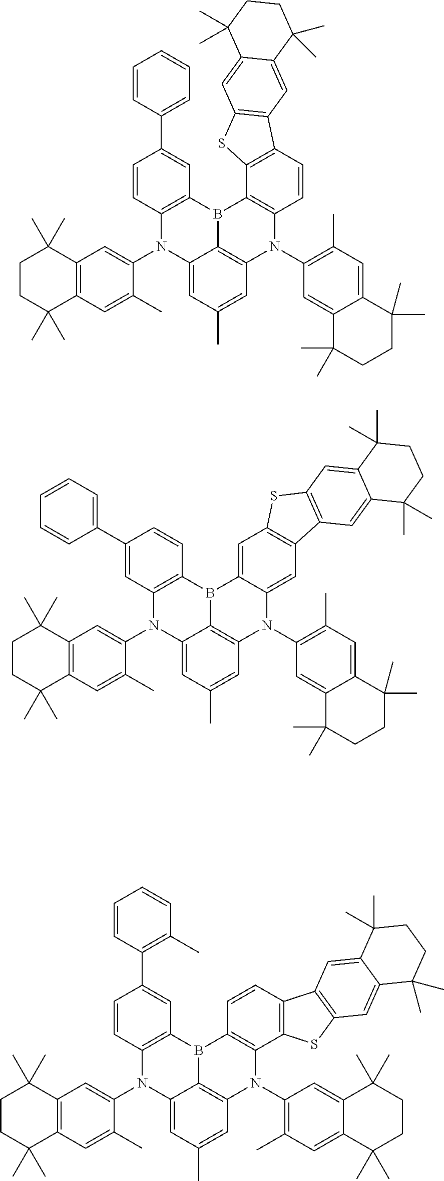 [SMILES: Cc1cc2c3c(c1)N(c1cc4c(cc1C)C(C)(C)CCC4(C)C)c1ccc4c(sc5cc6c(cc54)C(C)(C)CCC6(C)C)c1B3c1cc(-c3ccccc3)ccc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(-c3ccccc3)cc1N2c1cc2c(cc1C)C(C)(C)CCC2(C)C)sc1cc2c(cc14)C(C)(C)CCC2(C)C ; Cc1cc2c3c(c1)N(c1cc4c(cc1C)C(C)(C)CCC4(C)C)c1c(ccc4c1sc1cc5c(cc14)C(C)(C)CCC5(C)C)B3c1cc(-c3ccccc3C)ccc1N2c1cc2c(cc1C)C(C)(C)CCC2(C)C]

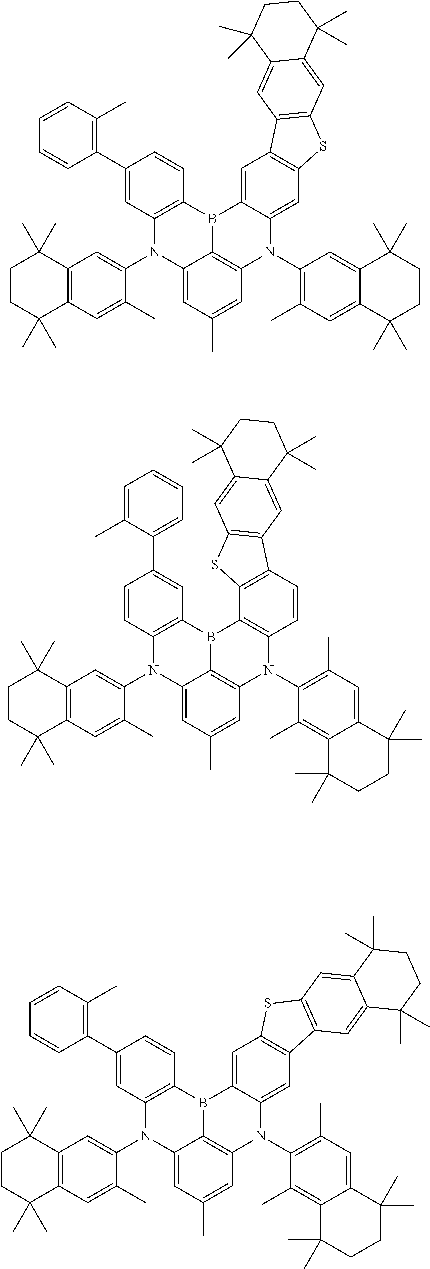 [SMILES: Cc1cc2c3c(c1)N(c1cc4c(cc1C)C(C)(C)CCC4(C)C)c1cc4sc5cc6c(cc5c4cc1B3c1ccc(-c3ccccc3C)cc1N2c1cc2c(cc1C)C(C)(C)CCC2(C)C)C(C)(C)CCC6(C)C ; Cc1cc2c3c(c1)N(c1c(C)cc4c(c1C)C(C)(C)CCC4(C)C)c1ccc4c(sc5cc6c(cc54)C(C)(C)CCC6(C)C)c1B3c1cc(-c3ccccc3C)ccc1N2c1cc2c(cc1C)C(C)(C)CCC2(C)C ; Cc1cc2c3c(c1)N(c1c(C)cc4c(c1C)C(C)(C)CCC4(C)C)c1cc4c(cc1B3c1ccc(-c3ccccc3C)cc1N2c1cc2c(cc1C)C(C)(C)CCC2(C)C)sc1cc2c(cc14)C(C)(C)CCC2(C)C]

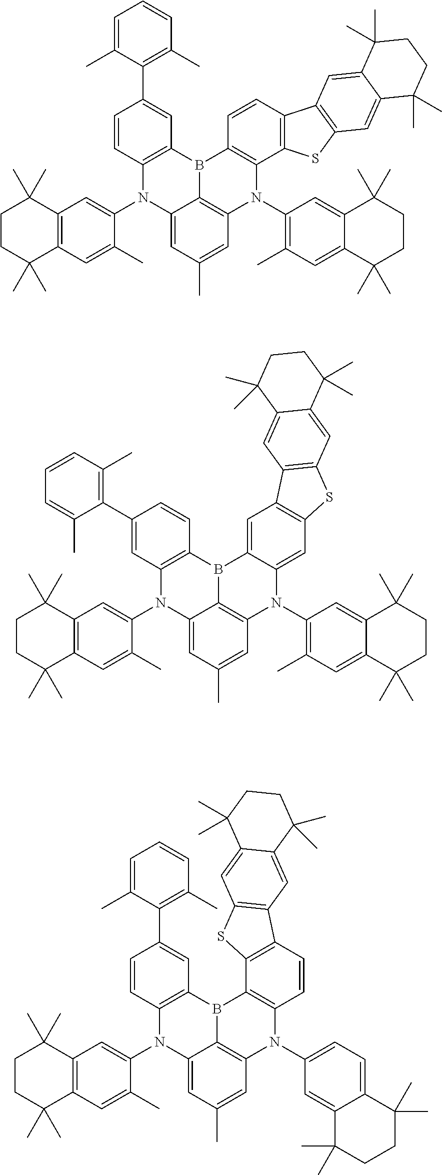 [SMILES: Cc1cc2c3c(c1)N(c1cc4c(cc1C)C(C)(C)CCC4(C)C)c1c(ccc4c1sc1cc5c(cc14)C(C)(C)CCC5(C)C)B3c1cc(-c3c(C)cccc3C)ccc1N2c1cc2c(cc1C)C(C)(C)CCC2(C)C ; Cc1cc2c3c(c1)N(c1cc4c(cc1C)C(C)(C)CCC4(C)C)c1cc4sc5cc6c(cc5c4cc1B3c1ccc(-c3c(C)cccc3C)cc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc(-c4c(C)cccc4C)cc1B3c1c(ccc3c1sc1cc4c(cc13)C(C)(C)CCC4(C)C)N2c1ccc2c(c1)C(C)(C)CCC2(C)C]

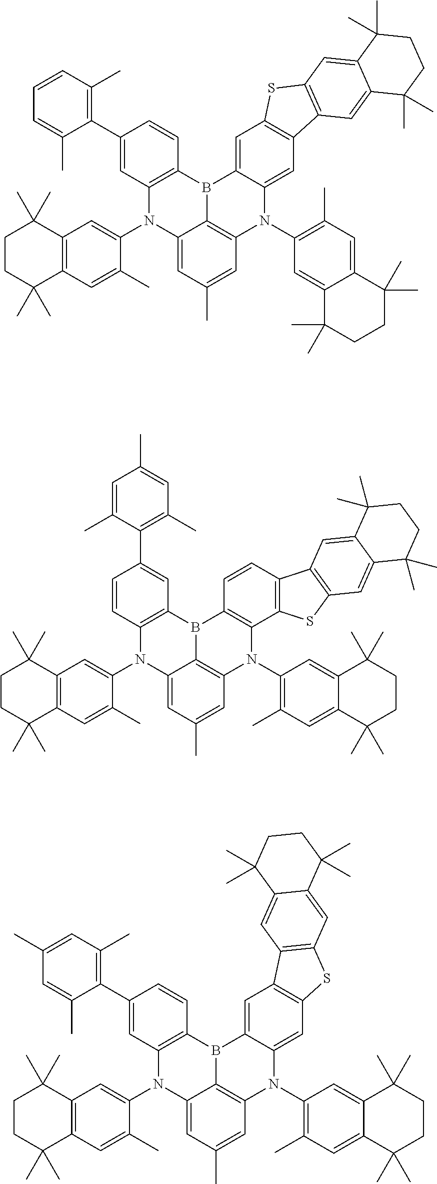 [SMILES: Cc1cc2c3c(c1)N(c1cc4c(cc1C)C(C)(C)CCC4(C)C)c1cc4c(cc1B3c1ccc(-c3c(C)cccc3C)cc1N2c1cc2c(cc1C)C(C)(C)CCC2(C)C)sc1cc2c(cc14)C(C)(C)CCC2(C)C ; Cc1cc(C)c(-c2ccc3c(c2)B2c4ccc5c(sc6cc7c(cc65)C(C)(C)CCC7(C)C)c4N(c4cc5c(cc4C)C(C)(C)CCC5(C)C)c4cc(C)cc(c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(C)cc4c2B3c2cc3c(cc2N4c2cc4c(cc2C)C(C)(C)CCC4(C)C)sc2cc4c(cc23)C(C)(C)CCC4(C)C)c(C)c1]

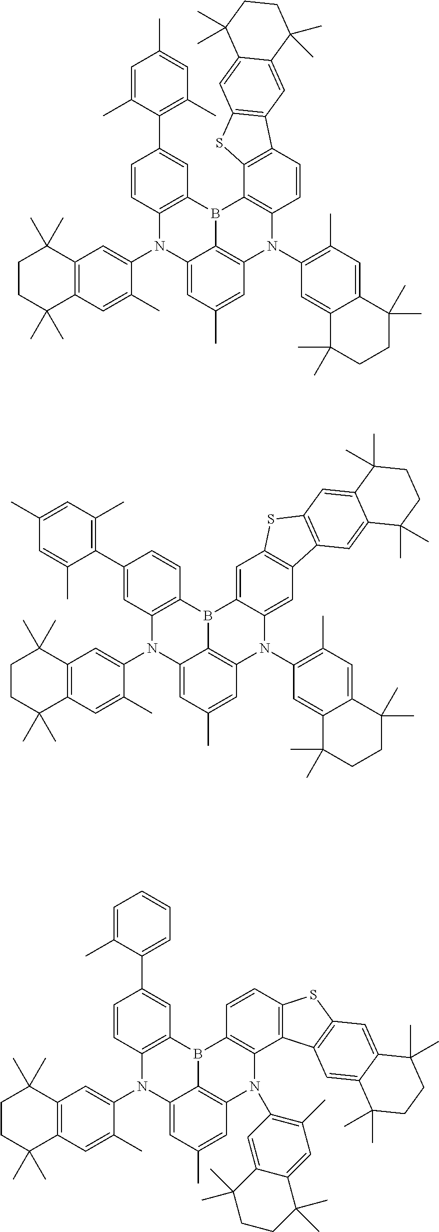 [SMILES: Cc1cc(C)c(-c2ccc3c(c2)B2c4c(cc(C)cc4N(c4cc5c(cc4C)C(C)(C)CCC5(C)C)c4ccc5c(sc6cc7c(cc65)C(C)(C)CCC7(C)C)c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(C)cc4c2B3c2cc3sc5cc6c(cc5c3cc2N4c2cc3c(cc2C)C(C)(C)CCC3(C)C)C(C)(C)CCC6(C)C)c(C)c1 ; Cc1cc2c3c(c1)N(c1cc4c(cc1C)C(C)(C)CCC4(C)C)c1c(ccc4sc5cc6c(cc5c14)C(C)(C)CCC6(C)C)B3c1cc(-c3ccccc3C)ccc1N2c1cc2c(cc1C)C(C)(C)CCC2(C)C]

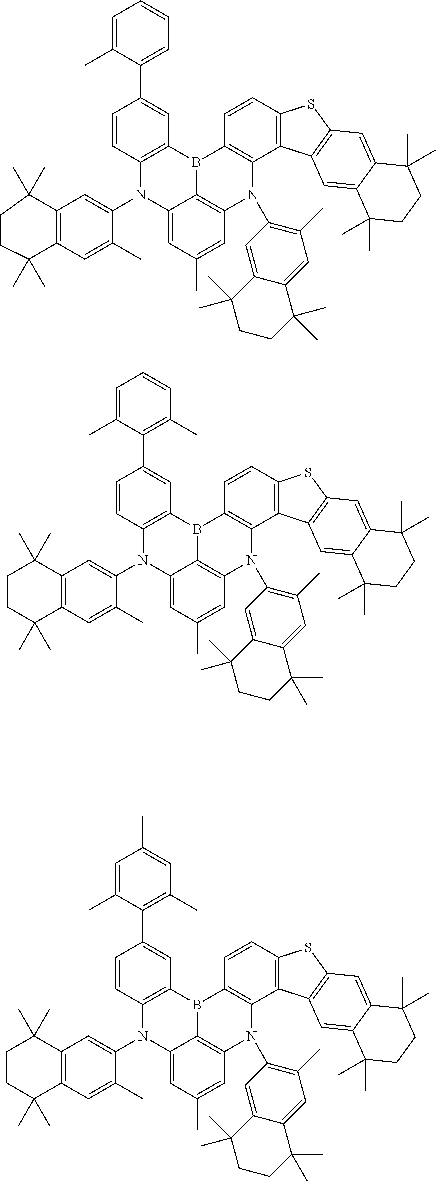 [SMILES: Cc1cc2c3c(c1)N(c1cc4c(cc1C)C(C)(C)CCC4(C)C)c1c(ccc4sc5cc6c(cc5c14)C(C)(C)CCC6(C)C)B3c1cc(-c3ccccc3C)ccc1N2c1cc2c(cc1C)C(C)(C)CCC2(C)C ; Cc1cc2c3c(c1)N(c1cc4c(cc1C)C(C)(C)CCC4(C)C)c1c(ccc4sc5cc6c(cc5c14)C(C)(C)CCC6(C)C)B3c1cc(-c3c(C)cccc3C)ccc1N2c1cc2c(cc1C)C(C)(C)CCC2(C)C ; Cc1cc(C)c(-c2ccc3c(c2)B2c4ccc5sc6cc7c(cc6c5c4N(c4cc5c(cc4C)C(C)(C)CCC5(C)C)c4cc(C)cc(c42)N3c2cc3c(cc2C)C(C)(C)CCC3(C)C)C(C)(C)CCC7(C)C)c(C)c1]

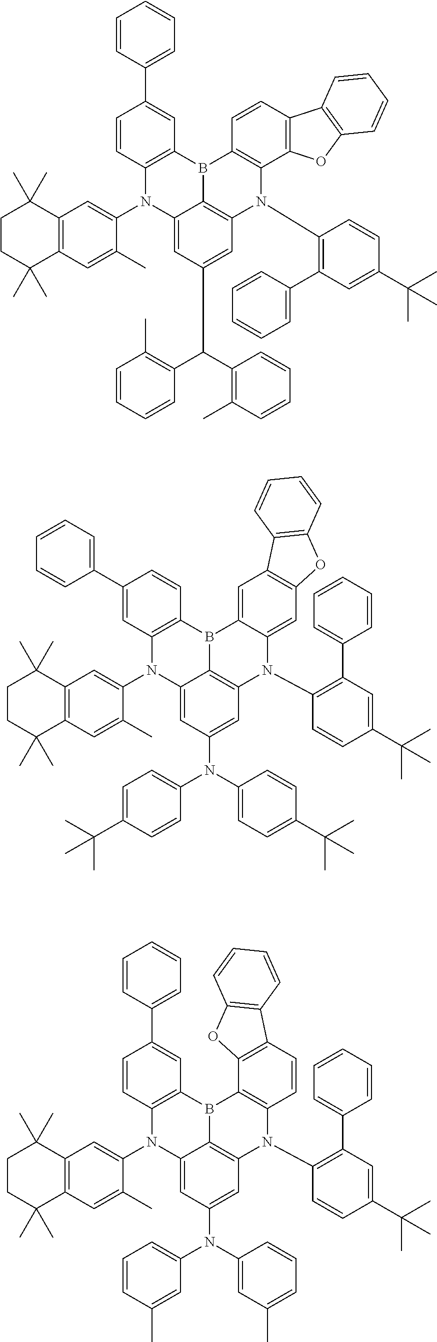 [SMILES: Cc1ccccc1C(c1cc2c3c(c1)N(c1ccc(C(C)(C)C)cc1-c1ccccc1)c1c(ccc4c1oc1ccccc14)B3c1cc(-c3ccccc3)ccc1N2c1cc2c(cc1C)C(C)(C)CCC2(C)C)c1ccccc1C ; Cc1cc2c(cc1N1c3cc(-c4ccccc4)ccc3B3c4cc5c(cc4N(c4ccc(C(C)(C)C)cc4-c4ccccc4)c4cc(N(c6ccc(C(C)(C)C)cc6)c6ccc(C(C)(C)C)cc6)cc1c43)oc1ccccc15)C(C)(C)CCC2(C)C ; Cc1cccc(N(c2cccc(C)c2)c2cc3c4c(c2)N(c2ccc(C(C)(C)C)cc2-c2ccccc2)c2ccc5c(oc6ccccc65)c2B4c2cc(-c4ccccc4)ccc2N3c2cc3c(cc2C)C(C)(C)CCC3(C)C)c1]

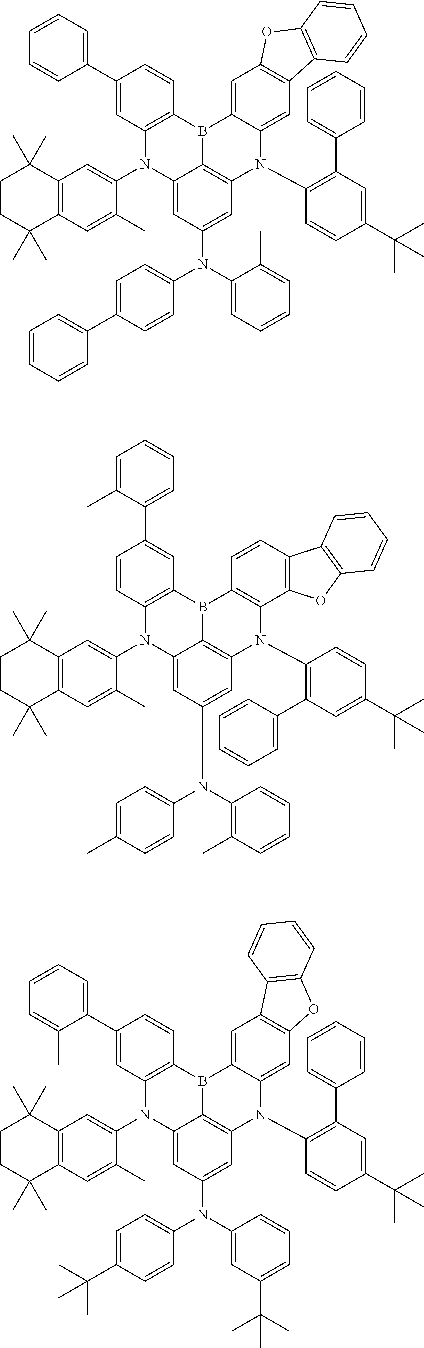 [SMILES: Cc1ccccc1N(c1ccc(-c2ccccc2)cc1)c1cc2c3c(c1)N(c1ccc(C(C)(C)C)cc1-c1ccccc1)c1cc4c(cc1B3c1ccc(-c3ccccc3)cc1N2c1cc2c(cc1C)C(C)(C)CCC2(C)C)oc1ccccc14 ; Cc1ccc(N(c2cc3c4c(c2)N(c2ccc(C(C)(C)C)cc2-c2ccccc2)c2c(ccc5c2oc2ccccc25)B4c2cc(-c4ccccc4C)ccc2N3c2cc3c(cc2C)C(C)(C)CCC3(C)C)c2ccccc2C)cc1 ; Cc1ccccc1-c1ccc2c(c1)N(c1cc3c(cc1C)C(C)(C)CCC3(C)C)c1cc(N(c3ccc(C(C)(C)C)cc3)c3cccc(C(C)(C)C)c3)cc3c1B2c1cc2c(cc1N3c1ccc(C(C)(C)C)cc1-c1ccccc1)oc1ccccc12]

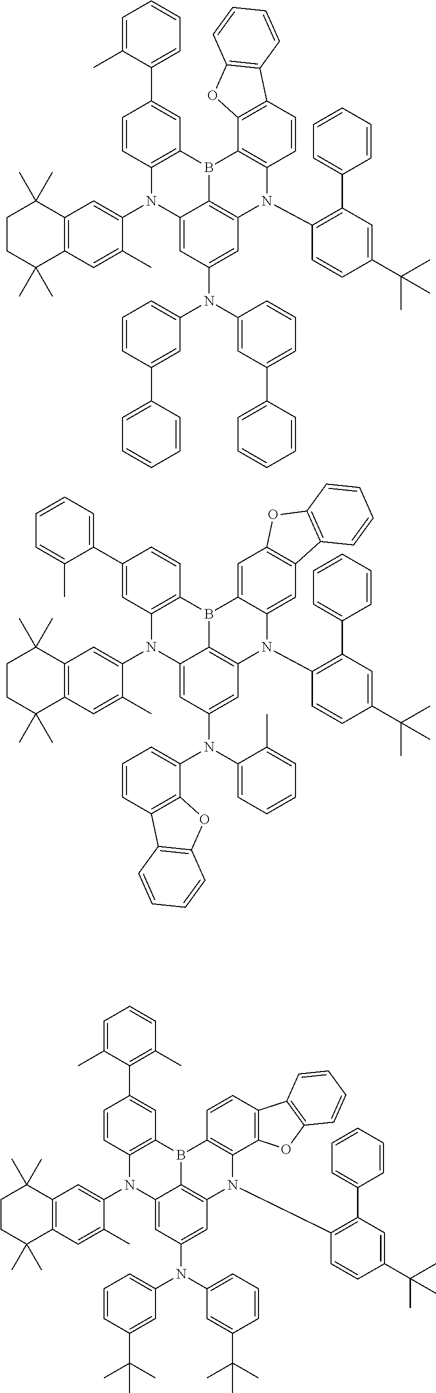

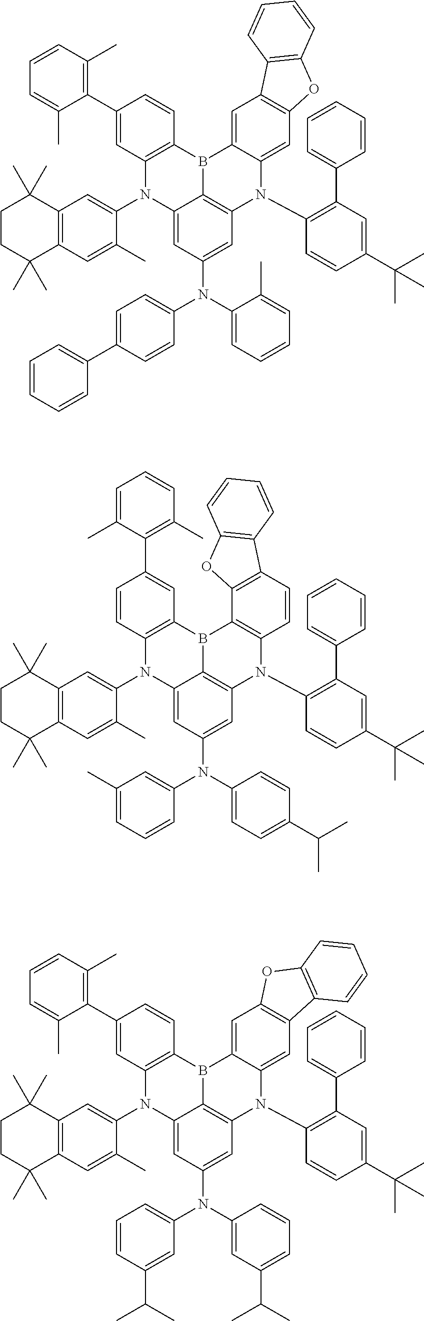 [SMILES: Cc1ccccc1N(c1ccc(-c2ccccc2)cc1)c1cc2c3c(c1)N(c1ccc(C(C)(C)C)cc1-c1ccccc1)c1cc4oc5ccccc5c4cc1B3c1ccc(-c3c(C)cccc3C)cc1N2c1cc2c(cc1C)C(C)(C)CCC2(C)C ; Cc1cccc(N(c2ccc(C(C)C)cc2)c2cc3c4c(c2)N(c2ccc(C(C)(C)C)cc2-c2ccccc2)c2ccc5c(oc6ccccc65)c2B4c2cc(-c4c(C)cccc4C)ccc2N3c2cc3c(cc2C)C(C)(C)CCC3(C)C)c1 ; Cc1cc2c(cc1N1c3cc(-c4c(C)cccc4C)ccc3B3c4cc5oc6ccccc6c5cc4N(c4ccc(C(C)(C)C)cc4-c4ccccc4)c4cc(N(c5cccc(C(C)C)c5)c5cccc(C(C)C)c5)cc1c43)C(C)(C)CCC2(C)C]

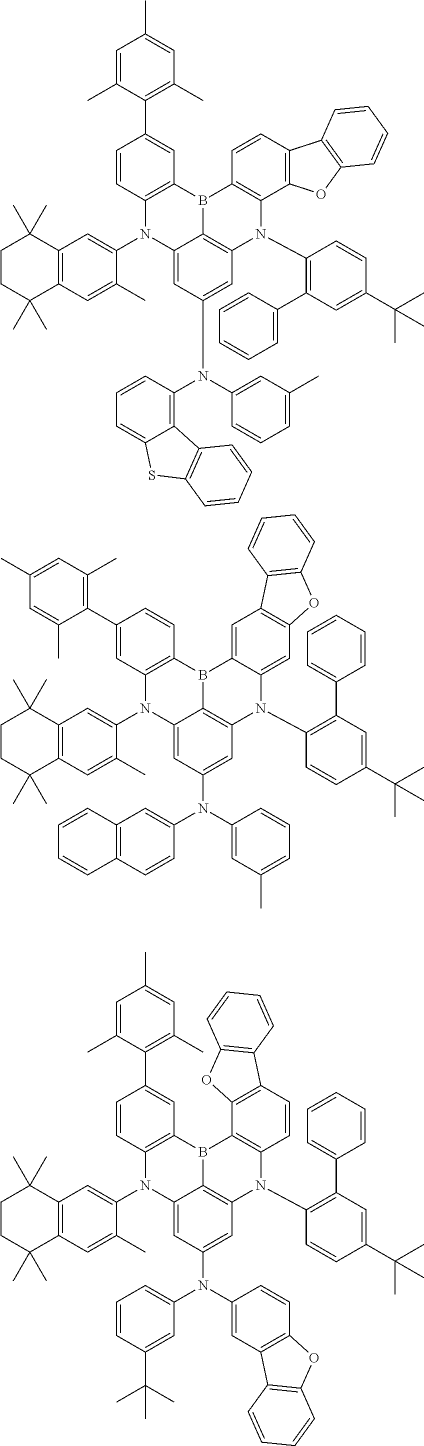

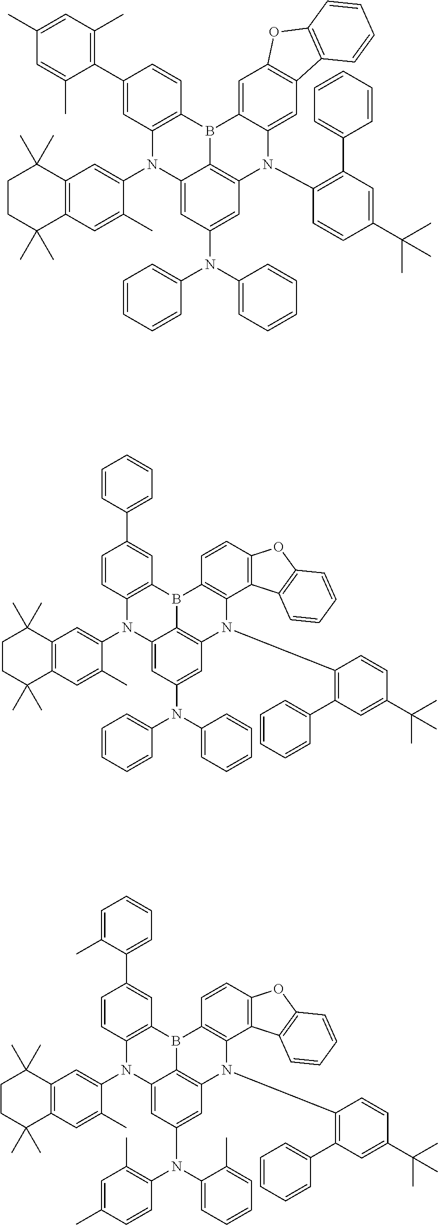 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3oc5ccccc5c3cc2N4c2ccc(C(C)(C)C)cc2-c2ccccc2)c(C)c1 ; Cc1cc2c(cc1N1c3ccc(-c4ccccc4)cc3B3c4ccc5oc6ccccc6c5c4N(c4ccc(C(C)(C)C)cc4-c4ccccc4)c4cc(N(c5ccccc5)c5ccccc5)cc1c43)C(C)(C)CCC2(C)C ; Cc1ccc(N(c2cc3c4c(c2)N(c2ccc(C(C)(C)C)cc2-c2ccccc2)c2c(ccc5oc6ccccc6c25)B4c2cc(-c4ccccc4C)ccc2N3c2cc3c(cc2C)C(C)(C)CCC3(C)C)c2ccccc2C)c(C)c1]

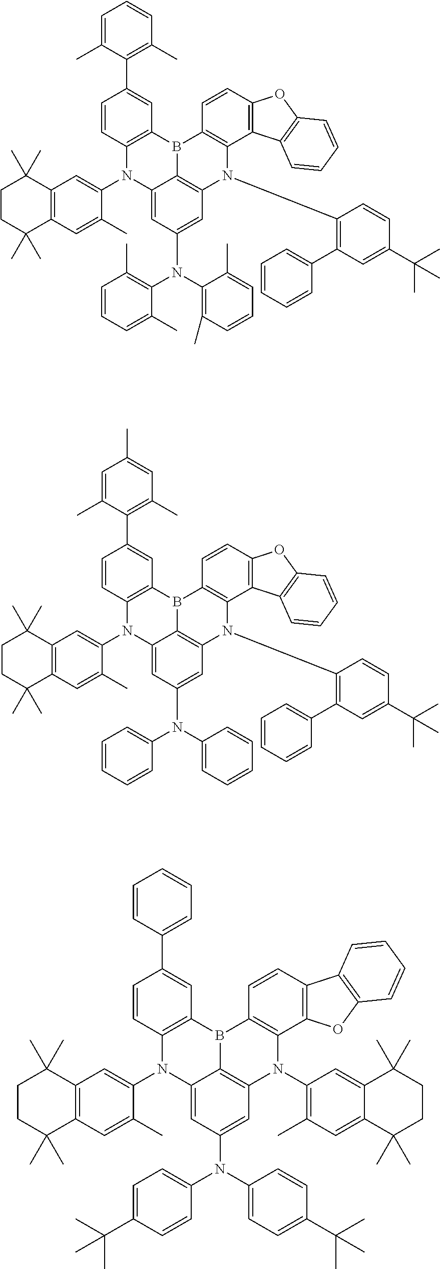 [SMILES: Cc1cc2c(cc1N1c3ccc(-c4c(C)cccc4C)cc3B3c4ccc5oc6ccccc6c5c4N(c4ccc(C(C)(C)C)cc4-c4ccccc4)c4cc(N(c5c(C)cccc5C)c5c(C)cccc5C)cc1c43)C(C)(C)CCC2(C)C ; Cc1cc(C)c(-c2ccc3c(c2)B2c4ccc5oc6ccccc6c5c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)c(C)c1 ; Cc1cc2c(cc1N1c3ccc(-c4ccccc4)cc3B3c4ccc5c(oc6ccccc65)c4N(c4cc5c(cc4C)C(C)(C)CCC5(C)C)c4cc(N(c5ccc(C(C)(C)C)cc5)c5ccc(C(C)(C)C)cc5)cc1c43)C(C)(C)CCC2(C)C]

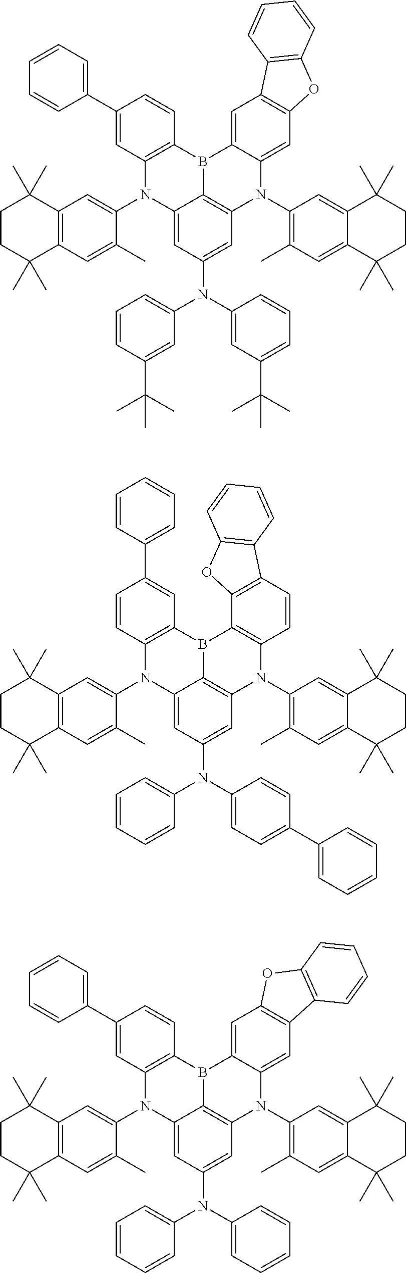 [SMILES: Cc1cc2c(cc1N1c3cc(-c4ccccc4)ccc3B3c4cc5c(cc4N(c4cc6c(cc4C)C(C)(C)CCC6(C)C)c4cc(N(c6cccc(C(C)(C)C)c6)c6cccc(C(C)(C)C)c6)cc1c43)oc1ccccc15)C(C)(C)CCC2(C)C ; Cc1cc2c(cc1N1c3ccc(-c4ccccc4)cc3B3c4c1cc(N(c1ccccc1)c1ccc(-c5ccccc5)cc1)cc4N(c1cc4c(cc1C)C(C)(C)CCC4(C)C)c1ccc4c(oc5ccccc54)c13)C(C)(C)CCC2(C)C ; Cc1cc2c(cc1N1c3cc(-c4ccccc4)ccc3B3c4cc5oc6ccccc6c5cc4N(c4cc5c(cc4C)C(C)(C)CCC5(C)C)c4cc(N(c5ccccc5)c5ccccc5)cc1c43)C(C)(C)CCC2(C)C]

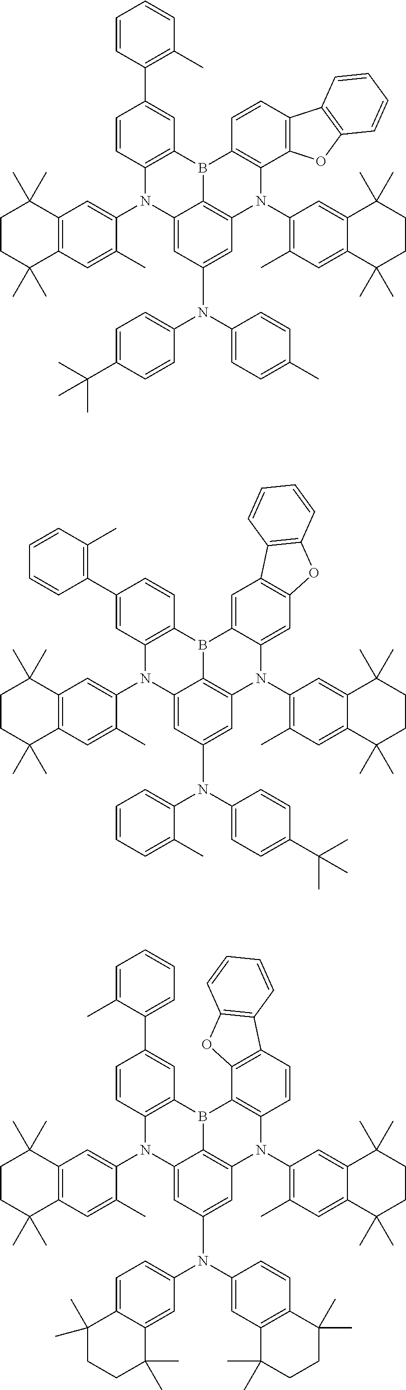 [SMILES: Cc1ccc(N(c2ccc(C(C)(C)C)cc2)c2cc3c4c(c2)N(c2cc5c(cc2C)C(C)(C)CCC5(C)C)c2c(ccc5c2oc2ccccc25)B4c2cc(-c4ccccc4C)ccc2N3c2cc3c(cc2C)C(C)(C)CCC3(C)C)cc1 ; Cc1ccccc1-c1ccc2c(c1)N(c1cc3c(cc1C)C(C)(C)CCC3(C)C)c1cc(N(c3ccc(C(C)(C)C)cc3)c3ccccc3C)cc3c1B2c1cc2c(cc1N3c1cc3c(cc1C)C(C)(C)CCC3(C)C)oc1ccccc12 ; Cc1ccccc1-c1ccc2c(c1)B1c3c(cc(N(c4ccc5c(c4)C(C)(C)CCC5(C)C)c4ccc5c(c4)C(C)(C)CCC5(C)C)cc3N(c3cc4c(cc3C)C(C)(C)CCC4(C)C)c3ccc4c(oc5ccccc54)c31)N2c1cc2c(cc1C)C(C)(C)CCC2(C)C]

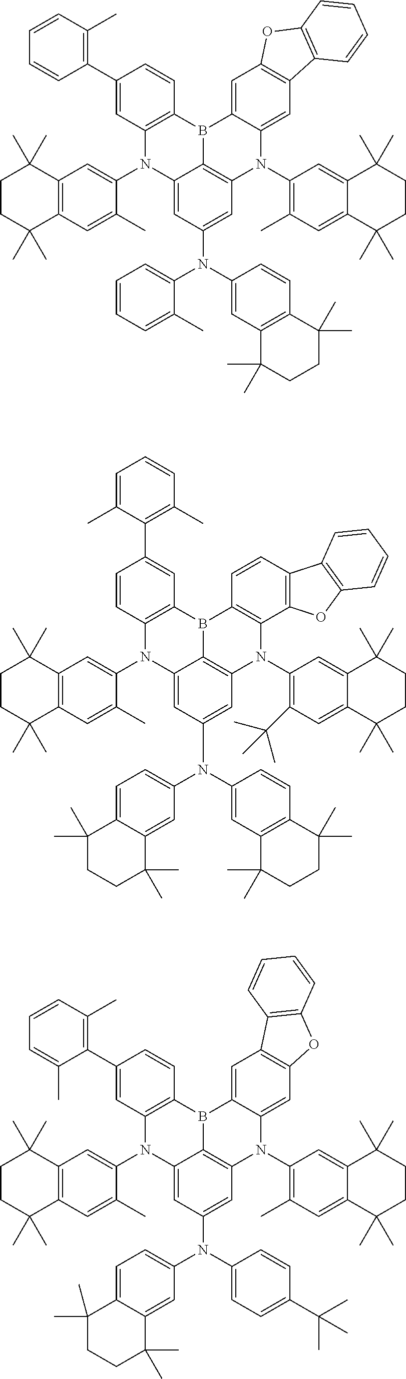 [SMILES: Cc1ccccc1-c1ccc2c(c1)N(c1cc3c(cc1C)C(C)(C)CCC3(C)C)c1cc(N(c3ccc4c(c3)C(C)(C)CCC4(C)C)c3ccccc3C)cc3c1B2c1cc2oc4ccccc4c2cc1N3c1cc2c(cc1C)C(C)(C)CCC2(C)C ; Cc1cc2c(cc1N1c3ccc(-c4c(C)cccc4C)cc3B3c4ccc5c(oc6ccccc65)c4N(c4cc5c(cc4C(C)(C)C)C(C)(C)CCC5(C)C)c4cc(N(c5ccc6c(c5)C(C)(C)CCC6(C)C)c5ccc6c(c5)C(C)(C)CCC6(C)C)cc1c43)C(C)(C)CCC2(C)C ; Cc1cc2c(cc1N1c3cc(-c4c(C)cccc4C)ccc3B3c4cc5c(cc4N(c4cc6c(cc4C)C(C)(C)CCC6(C)C)c4cc(N(c6ccc(C(C)(C)C)cc6)c6ccc7c(c6)C(C)(C)CCC7(C)C)cc1c43)oc1ccccc15)C(C)(C)CCC2(C)C]

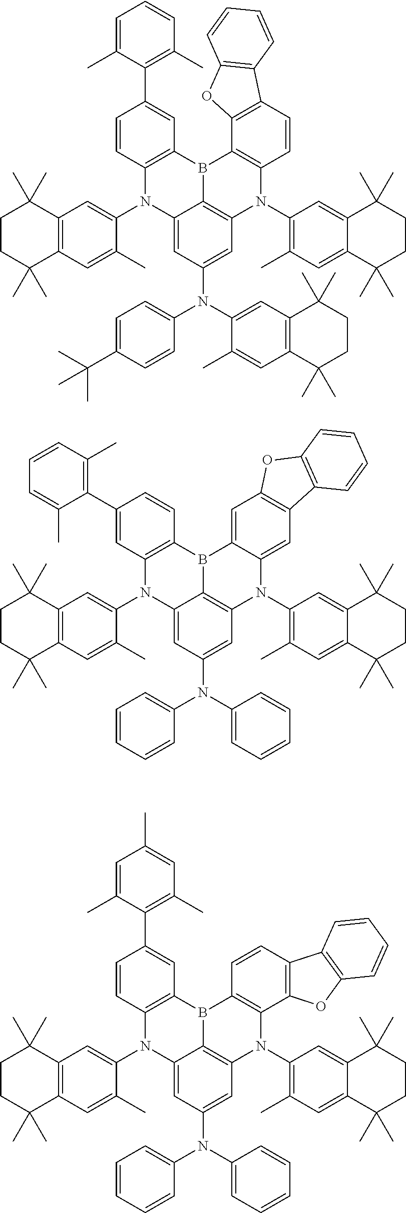

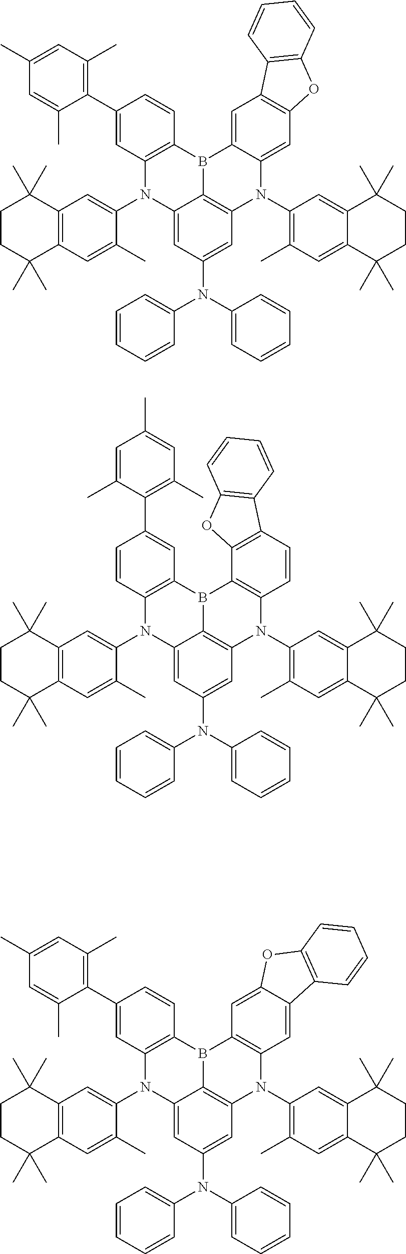

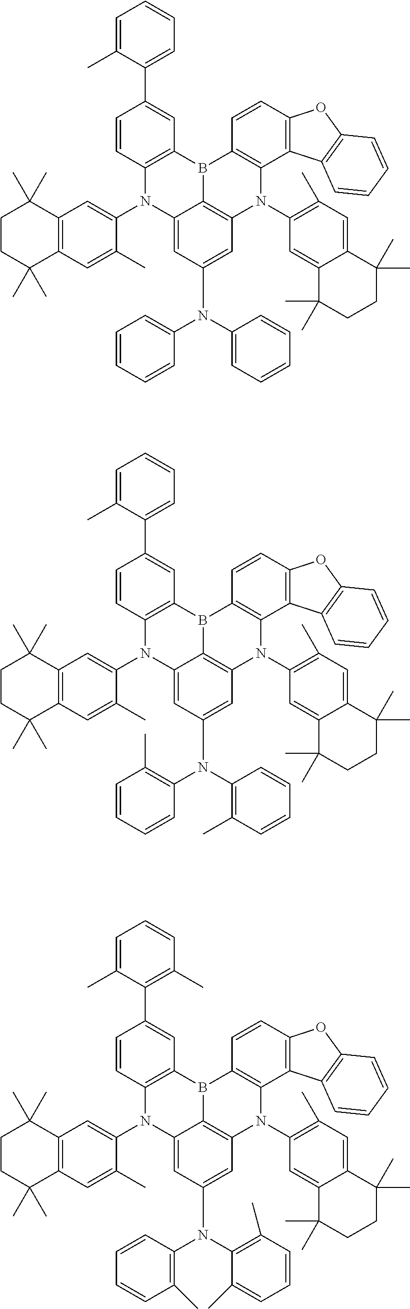 [SMILES: Cc1ccccc1-c1ccc2c(c1)B1c3ccc4oc5ccccc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C ; Cc1ccccc1-c1ccc2c(c1)B1c3ccc4oc5ccccc5c4c3N(c3cc4c(cc3C)C(C)(C)CCC4(C)C)c3cc(N(c4ccccc4C)c4ccccc4C)cc(c31)N2c1cc2c(cc1C)C(C)(C)CCC2(C)C ; Cc1cc2c(cc1N1c3ccc(-c4c(C)cccc4C)cc3B3c4ccc5oc6ccccc6c5c4N(c4cc5c(cc4C)C(C)(C)CCC5(C)C)c4cc(N(c5ccccc5C)c5c(C)cccc5C)cc1c43)C(C)(C)CCC2(C)C]

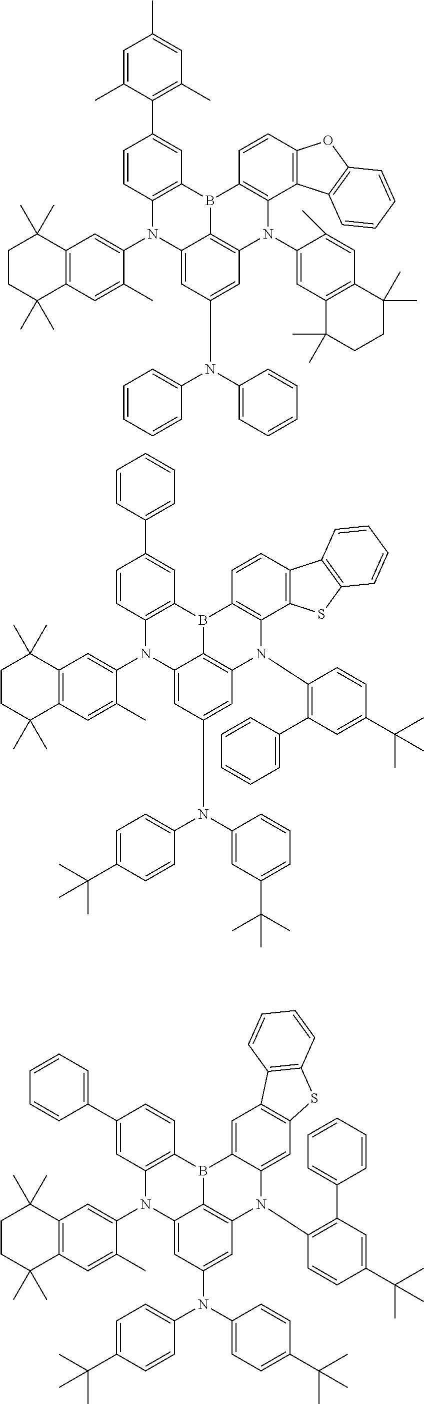

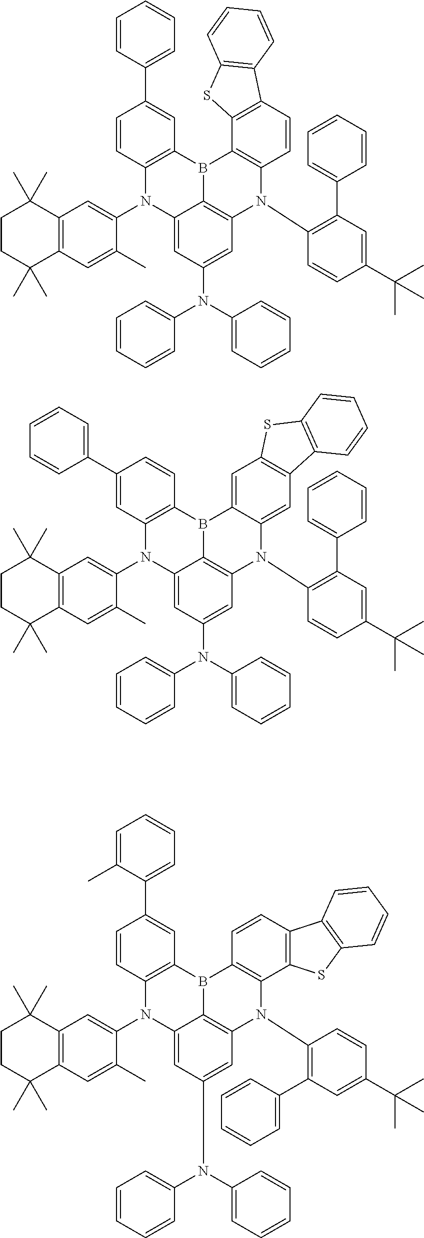 [SMILES: Cc1cc2c(cc1N1c3ccc(-c4ccccc4)cc3B3c4c1cc(N(c1ccccc1)c1ccccc1)cc4N(c1ccc(C(C)(C)C)cc1-c1ccccc1)c1ccc4c(sc5ccccc54)c13)C(C)(C)CCC2(C)C ; Cc1cc2c(cc1N1c3cc(-c4ccccc4)ccc3B3c4cc5sc6ccccc6c5cc4N(c4ccc(C(C)(C)C)cc4-c4ccccc4)c4cc(N(c5ccccc5)c5ccccc5)cc1c43)C(C)(C)CCC2(C)C ; Cc1ccccc1-c1ccc2c(c1)B1c3ccc4c(sc5ccccc54)c3N(c3ccc(C(C)(C)C)cc3-c3ccccc3)c3cc(N(c4ccccc4)c4ccccc4)cc(c31)N2c1cc2c(cc1C)C(C)(C)CCC2(C)C]

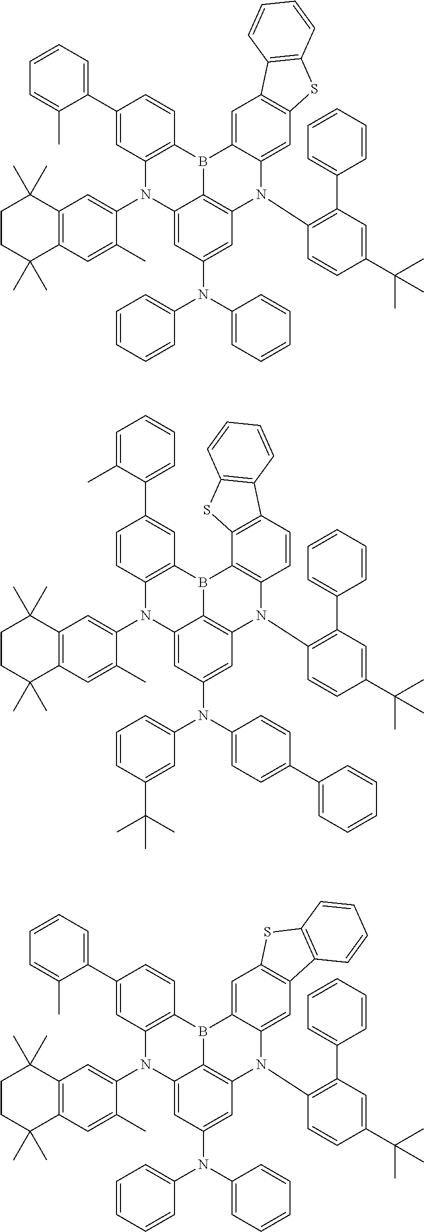 [SMILES: Cc1ccccc1-c1ccc2c(c1)N(c1cc3c(cc1C)C(C)(C)CCC3(C)C)c1cc(N(c3ccccc3)c3ccccc3)cc3c1B2c1cc2c(cc1N3c1ccc(C(C)(C)C)cc1-c1ccccc1)sc1ccccc12 ; Cc1ccccc1-c1ccc2c(c1)B1c3c(cc(N(c4ccc(-c5ccccc5)cc4)c4cccc(C(C)(C)C)c4)cc3N(c3ccc(C(C)(C)C)cc3-c3ccccc3)c3ccc4c(sc5ccccc54)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2sc4ccccc4c2cc1N3c1ccc(C(C)(C)C)cc1-c1ccccc1]

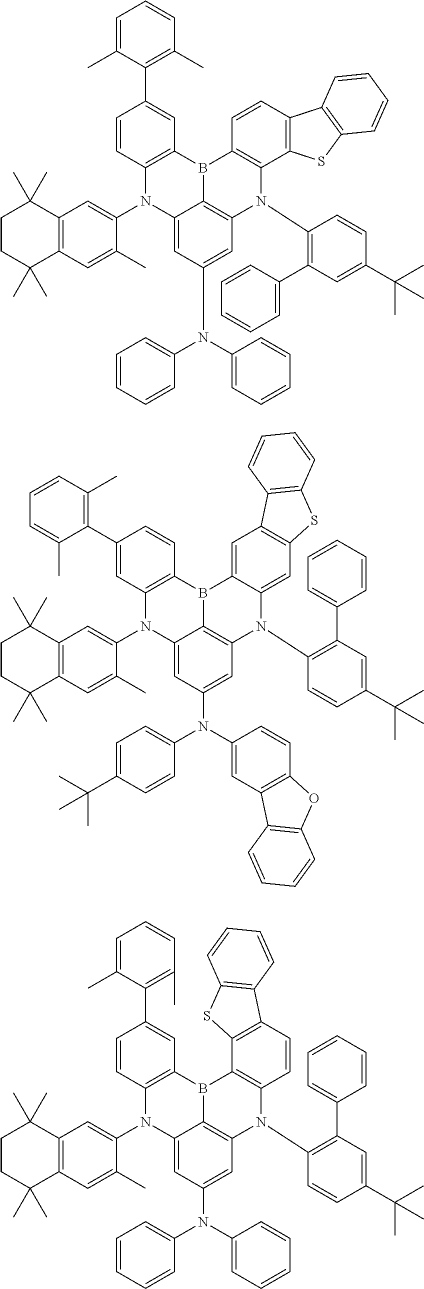

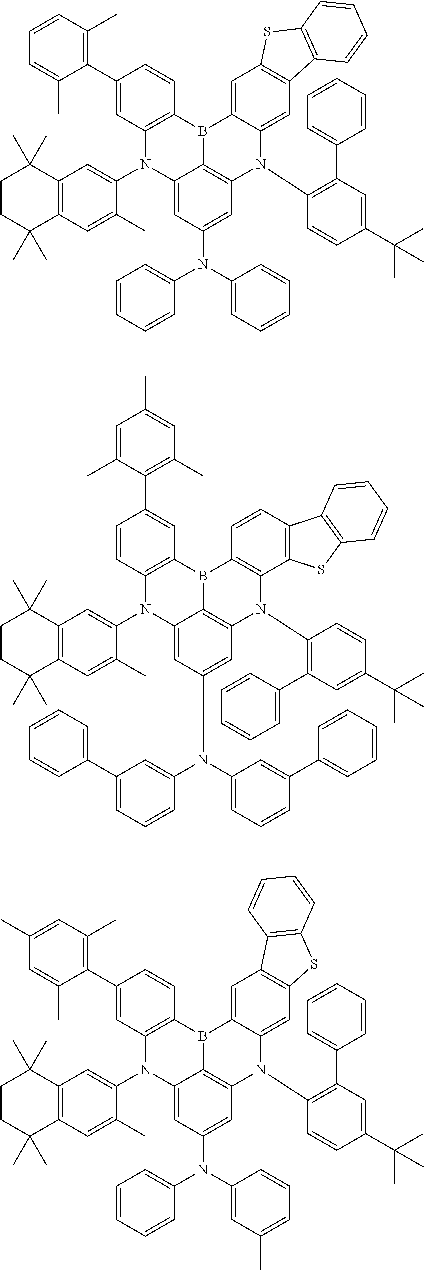

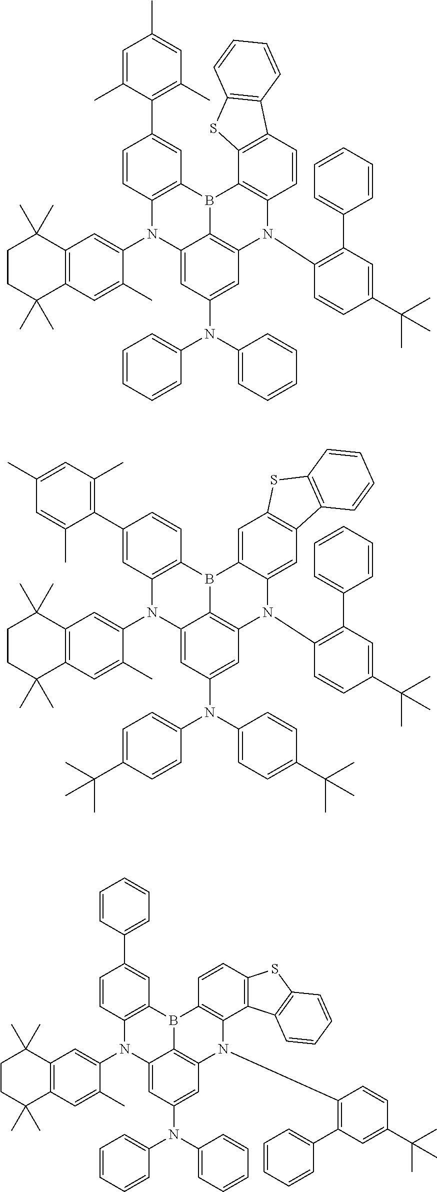 [SMILES: Cc1cc(C)c(-c2ccc3c(c2)B2c4c(cc(N(c5ccccc5)c5ccccc5)cc4N(c4ccc(C(C)(C)C)cc4-c4ccccc4)c4ccc5c(sc6ccccc65)c42)N3c2cc3c(cc2C)C(C)(C)CCC3(C)C)c(C)c1 ; Cc1cc(C)c(-c2ccc3c(c2)N(c2cc4c(cc2C)C(C)(C)CCC4(C)C)c2cc(N(c4ccc(C(C)(C)C)cc4)c4ccc(C(C)(C)C)cc4)cc4c2B3c2cc3sc5ccccc5c3cc2N4c2ccc(C(C)(C)C)cc2-c2ccccc2)c(C)c1 ; Cc1cc2c(cc1N1c3ccc(-c4ccccc4)cc3B3c4ccc5sc6ccccc6c5c4N(c4ccc(C(C)(C)C)cc4-c4ccccc4)c4cc(N(c5ccccc5)c5ccccc5)cc1c43)C(C)(C)CCC2(C)C]

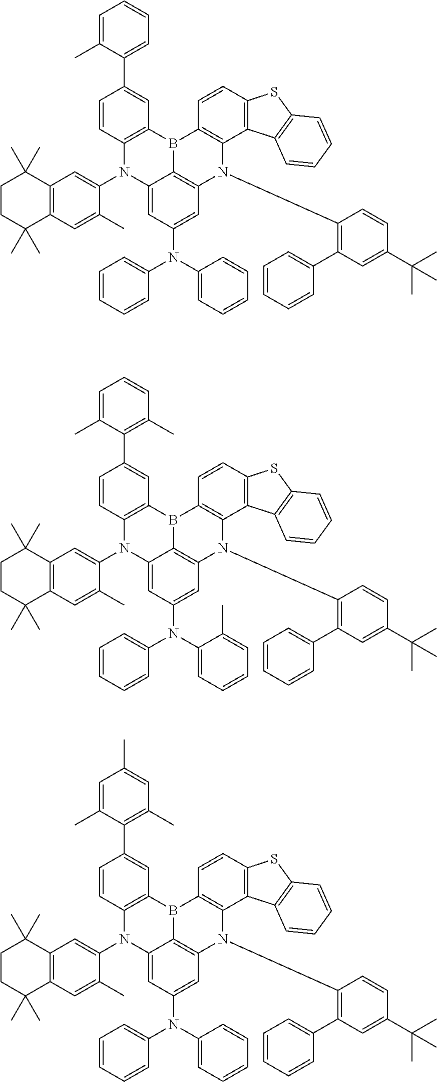 [SMILES: Cc1ccccc1-c1ccc2c(c1)B1c3ccc4sc5ccccc5c4c3N(c3ccc(C(C)(C)C)cc3-c3ccccc3)c3cc(N(c4ccccc4)c4ccccc4)cc(c31)N2c1cc2c(cc1C)C(C)(C)CCC2(C)C ; Cc1ccccc1N(c1ccccc1)c1cc2c3c(c1)N(c1ccc(C(C)(C)C)cc1-c1ccccc1)c1c(ccc4sc5ccccc5c14)B3c1cc(-c3c(C)cccc3C)ccc1N2c1cc2c(cc1C)C(C)(C)CCC2(C)C ; Cc1cc(C)c(-c2ccc3c(c2)B2c4ccc5sc6ccccc6c5c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)c(C)c1]

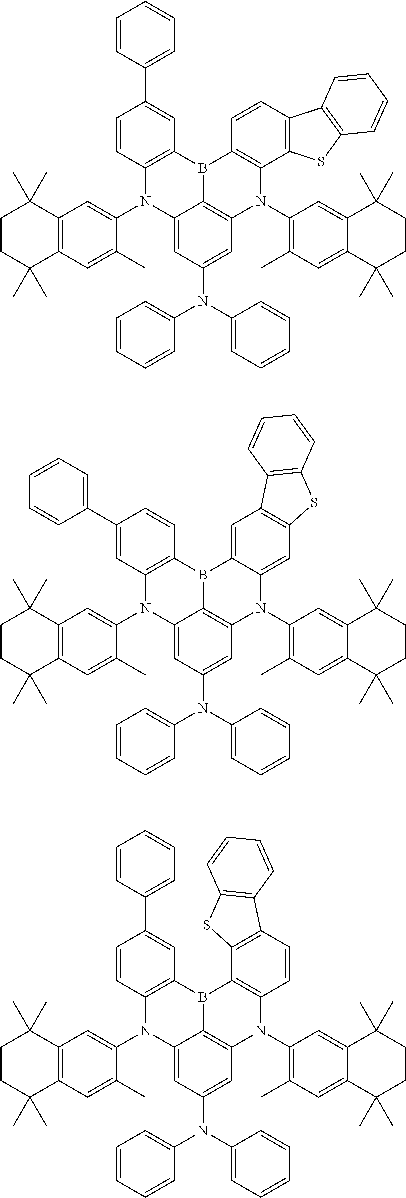 [SMILES: Cc1cc2c(cc1N1c3ccc(-c4ccccc4)cc3B3c4ccc5c(sc6ccccc65)c4N(c4cc5c(cc4C)C(C)(C)CCC5(C)C)c4cc(N(c5ccccc5)c5ccccc5)cc1c43)C(C)(C)CCC2(C)C ; Cc1cc2c(cc1N1c3cc(-c4ccccc4)ccc3B3c4cc5c(cc4N(c4cc6c(cc4C)C(C)(C)CCC6(C)C)c4cc(N(c6ccccc6)c6ccccc6)cc1c43)sc1ccccc15)C(C)(C)CCC2(C)C ; Cc1cc2c(cc1N1c3ccc(-c4ccccc4)cc3B3c4c1cc(N(c1ccccc1)c1ccccc1)cc4N(c1cc4c(cc1C)C(C)(C)CCC4(C)C)c1ccc4c(sc5ccccc54)c13)C(C)(C)CCC2(C)C]

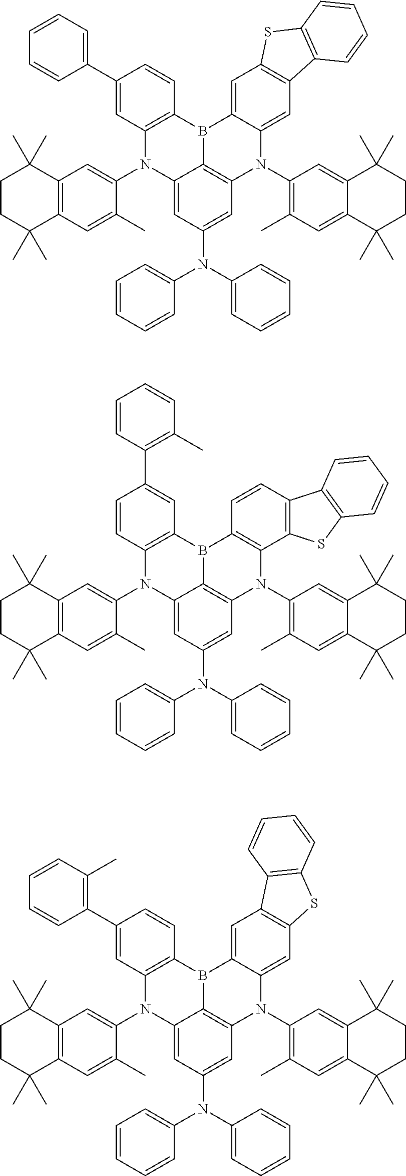 [SMILES: Cc1cc2c(cc1N1c3cc(-c4ccccc4)ccc3B3c4cc5sc6ccccc6c5cc4N(c4cc5c(cc4C)C(C)(C)CCC5(C)C)c4cc(N(c5ccccc5)c5ccccc5)cc1c43)C(C)(C)CCC2(C)C ; Cc1ccccc1-c1ccc2c(c1)B1c3ccc4c(sc5ccccc54)c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2c(cc1N3c1cc3c(cc1C)C(C)(C)CCC3(C)C)sc1ccccc12]

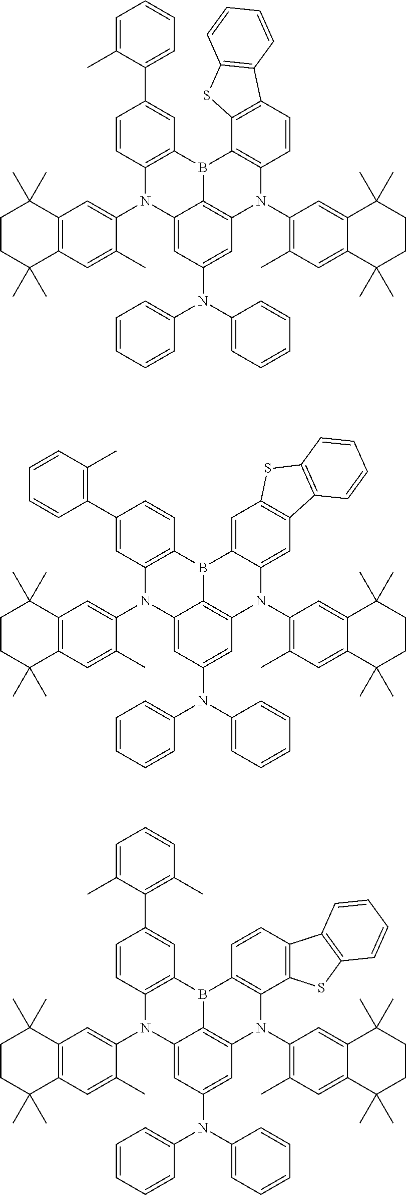 [SMILES: Cc1ccccc1-c1ccc2c(c1)B1c3c(cc(N(c4ccccc4)c4ccccc4)cc3N(c3cc4c(cc3C)C(C)(C)CCC4(C)C)c3ccc4c(sc5ccccc54)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2sc4ccccc4c2cc1N3c1cc2c(cc1C)C(C)(C)CCC2(C)C ; Cc1cc2c(cc1N1c3ccc(-c4c(C)cccc4C)cc3B3c4ccc5c(sc6ccccc65)c4N(c4cc5c(cc4C)C(C)(C)CCC5(C)C)c4cc(N(c5ccccc5)c5ccccc5)cc1c43)C(C)(C)CCC2(C)C]

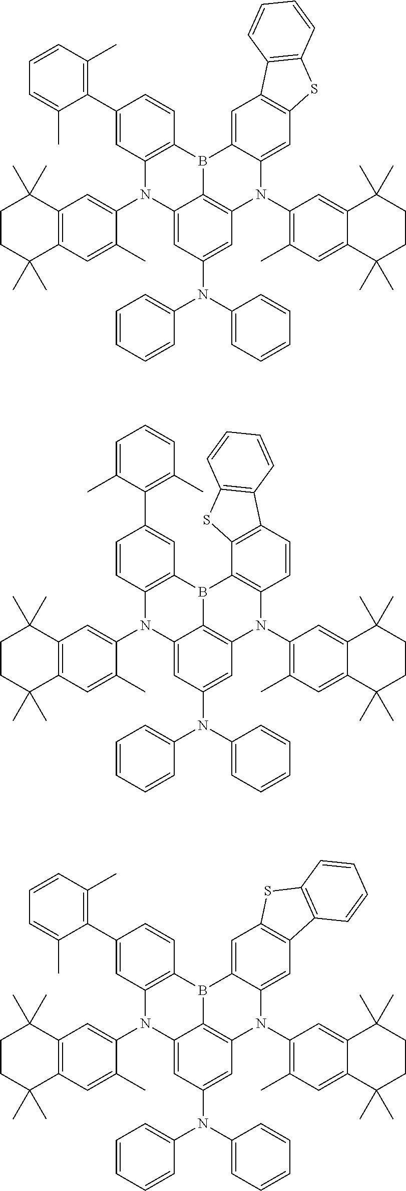 [SMILES: Cc1cc2c(cc1N1c3cc(-c4c(C)cccc4C)ccc3B3c4cc5c(cc4N(c4cc6c(cc4C)C(C)(C)CCC6(C)C)c4cc(N(c6ccccc6)c6ccccc6)cc1c43)sc1ccccc15)C(C)(C)CCC2(C)C ; Cc1cc2c(cc1N1c3ccc(-c4c(C)cccc4C)cc3B3c4c1cc(N(c1ccccc1)c1ccccc1)cc4N(c1cc4c(cc1C)C(C)(C)CCC4(C)C)c1ccc4c(sc5ccccc54)c13)C(C)(C)CCC2(C)C ; Cc1cc2c(cc1N1c3cc(-c4c(C)cccc4C)ccc3B3c4cc5sc6ccccc6c5cc4N(c4cc5c(cc4C)C(C)(C)CCC5(C)C)c4cc(N(c5ccccc5)c5ccccc5)cc1c43)C(C)(C)CCC2(C)C]

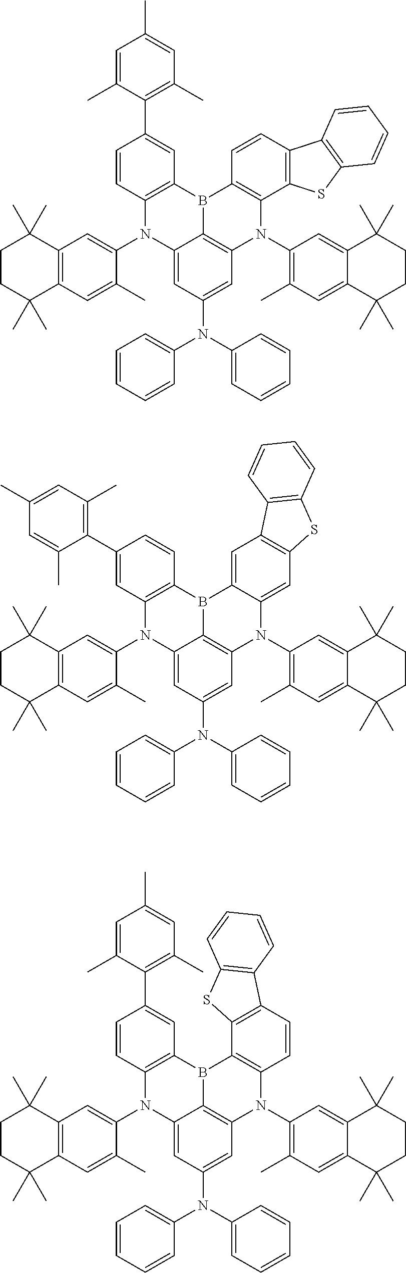

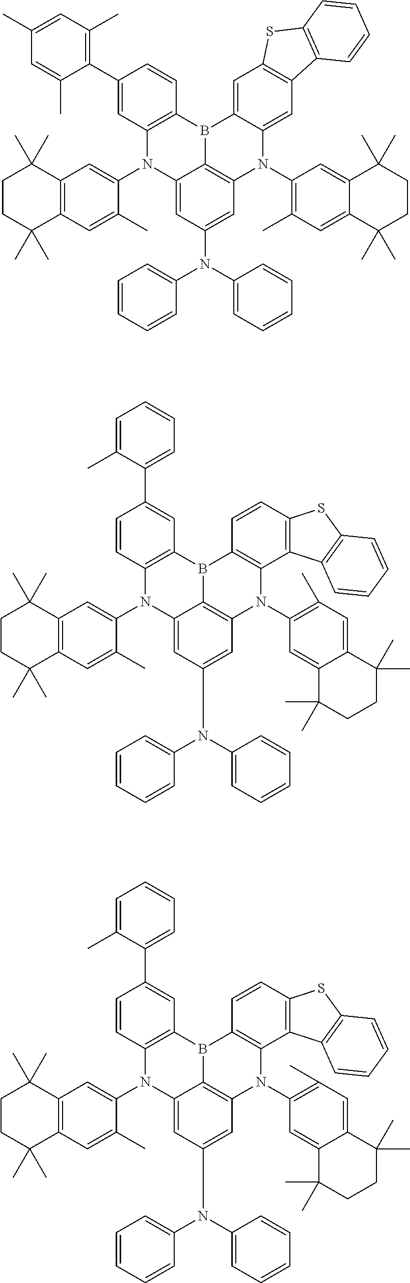 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3sc5ccccc5c3cc2N4c2cc3c(cc2C)C(C)(C)CCC3(C)C)c(C)c1 ; Cc1ccccc1-c1ccc2c(c1)B1c3ccc4sc5ccccc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C ; Cc1ccccc1-c1ccc2c(c1)B1c3ccc4sc5ccccc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C]

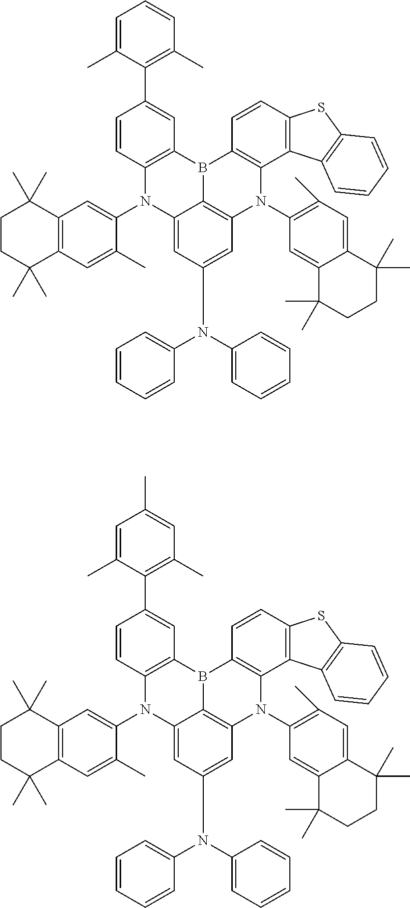 [SMILES: Cc1cc2c(cc1N1c3ccc(-c4c(C)cccc4C)cc3B3c4ccc5sc6ccccc6c5c4N(c4cc5c(cc4C)C(C)(C)CCC5(C)C)c4cc(N(c5ccccc5)c5ccccc5)cc1c43)C(C)(C)CCC2(C)C ; Cc1cc(C)c(-c2ccc3c(c2)B2c4ccc5sc6ccccc6c5c4N(c4cc5c(cc4C)C(C)(C)CCC5(C)C)c4cc(N(c5ccccc5)c5ccccc5)cc(c42)N3c2cc3c(cc2C)C(C)(C)CCC3(C)C)c(C)c1]

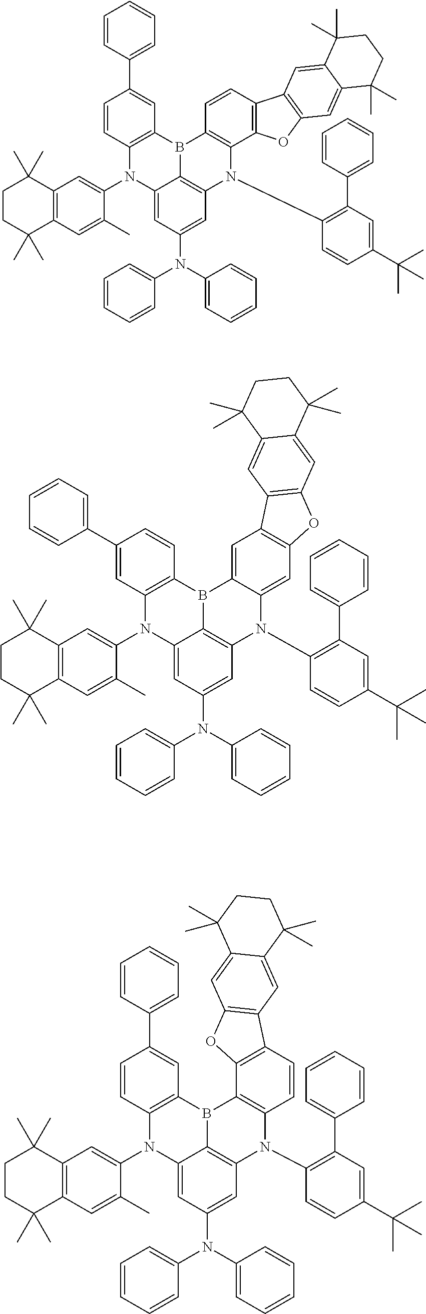 [SMILES: Cc1cc2c(cc1N1c3ccc(-c4ccccc4)cc3B3c4ccc5c(oc6cc7c(cc65)C(C)(C)CCC7(C)C)c4N(c4ccc(C(C)(C)C)cc4-c4ccccc4)c4cc(N(c5ccccc5)c5ccccc5)cc1c43)C(C)(C)CCC2(C)C ; Cc1cc2c(cc1N1c3cc(-c4ccccc4)ccc3B3c4cc5c(cc4N(c4ccc(C(C)(C)C)cc4-c4ccccc4)c4cc(N(c6ccccc6)c6ccccc6)cc1c43)oc1cc3c(cc15)C(C)(C)CCC3(C)C)C(C)(C)CCC2(C)C ; Cc1cc2c(cc1N1c3ccc(-c4ccccc4)cc3B3c4c1cc(N(c1ccccc1)c1ccccc1)cc4N(c1ccc(C(C)(C)C)cc1-c1ccccc1)c1ccc4c(oc5cc6c(cc54)C(C)(C)CCC6(C)C)c13)C(C)(C)CCC2(C)C]

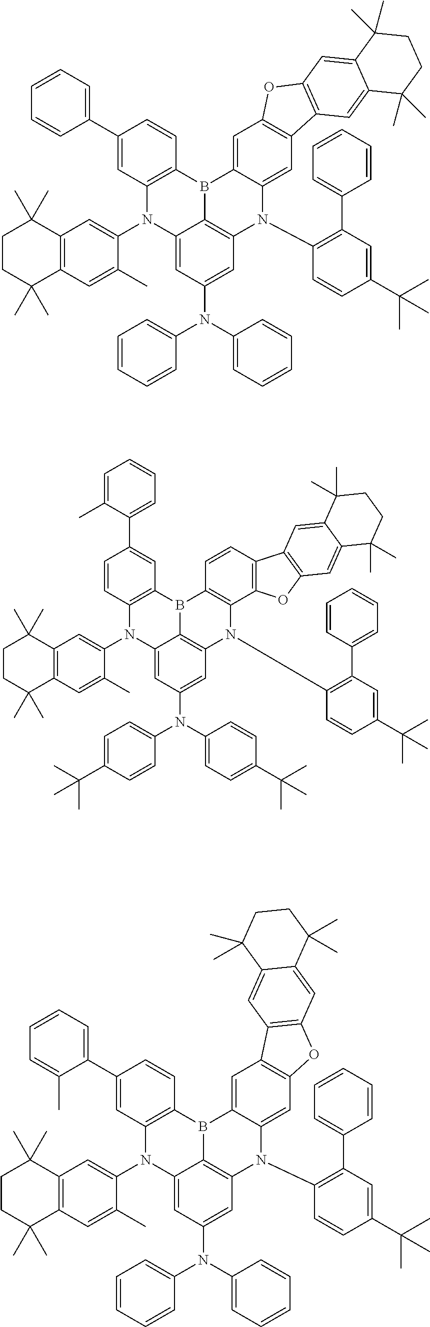 [SMILES: Cc1cc2c(cc1N1c3cc(-c4ccccc4)ccc3B3c4cc5oc6cc7c(cc6c5cc4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1ccccc1-c1ccc2c(c1)B1c3ccc4c(oc5cc6c(cc54)C(C)(C)CCC6(C)C)c3N(c3ccc(C(C)(C)C)cc3-c3ccccc3)c3cc(N(c4ccc(C(C)(C)C)cc4)c4ccc(C(C)(C)C)cc4)cc(c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2c(cc1N3c1ccc(C(C)(C)C)cc1-c1ccccc1)oc1cc3c(cc12)C(C)(C)CCC3(C)C]

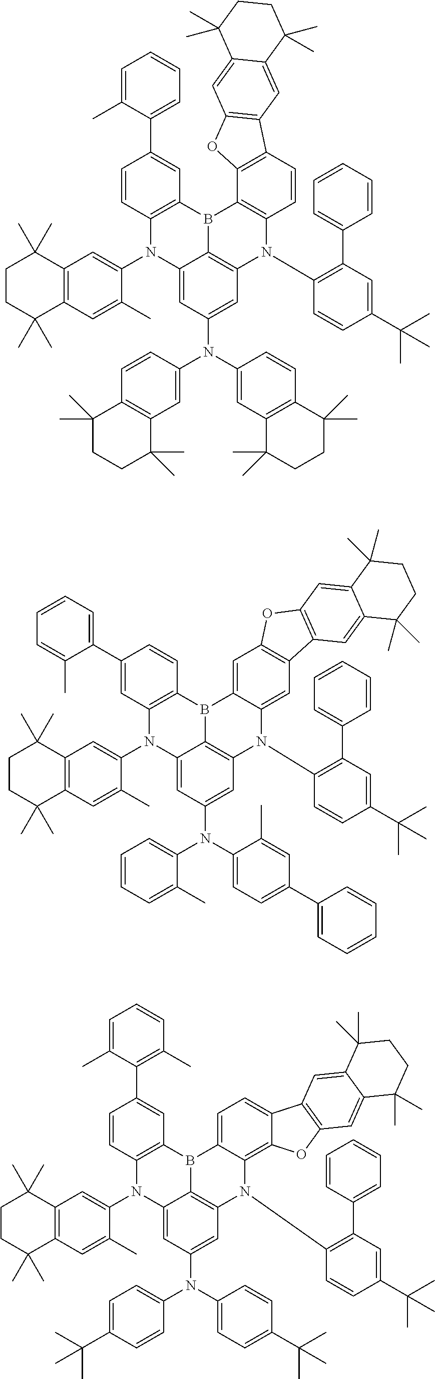

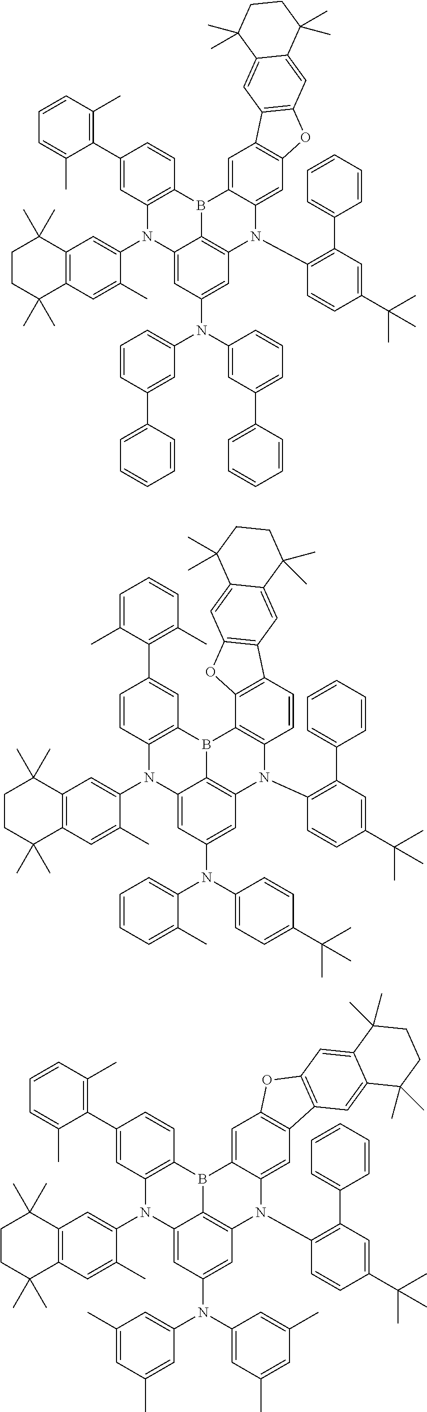

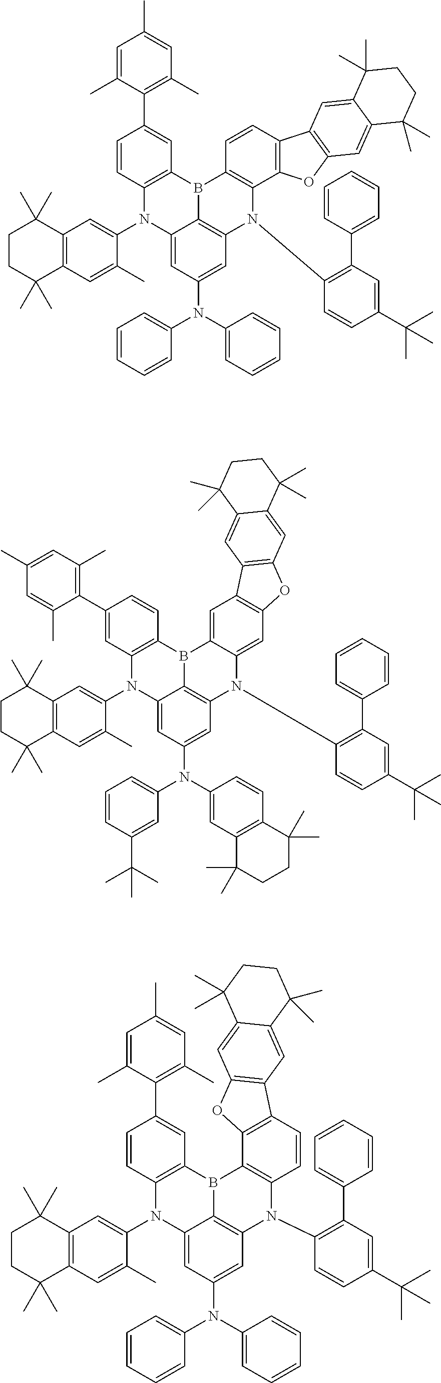

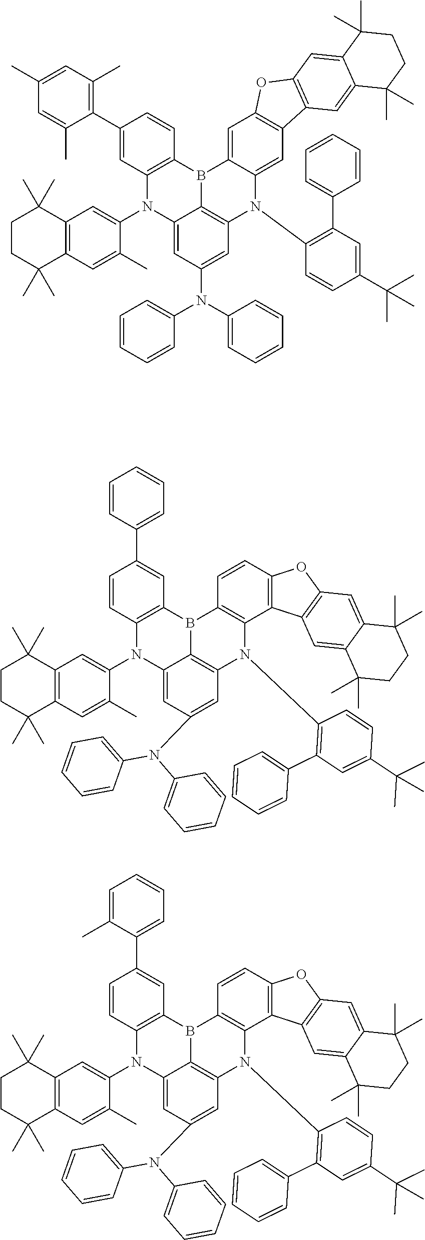 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3oc5cc6c(cc5c3cc2N4c2ccc(C(C)(C)C)cc2-c2ccccc2)C(C)(C)CCC6(C)C)c(C)c1 ; Cc1cc2c(cc1N1c3ccc(-c4ccccc4)cc3B3c4ccc5oc6cc7c(cc6c5c4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1ccccc1-c1ccc2c(c1)B1c3ccc4oc5cc6c(cc5c4c3N(c3ccc(C(C)(C)C)cc3-c3ccccc3)c3cc(N(c4ccccc4)c4ccccc4)cc(c31)N2c1cc2c(cc1C)C(C)(C)CCC2(C)C)C(C)(C)CCC6(C)C]

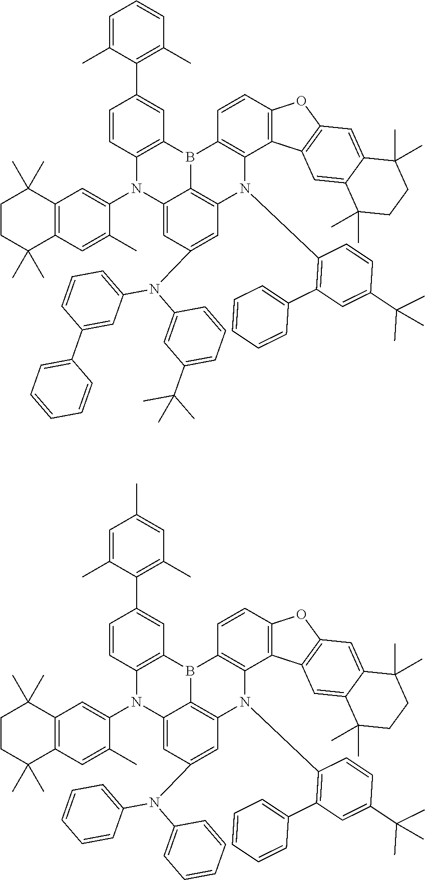 [SMILES: Cc1cc2c(cc1N1c3ccc(-c4c(C)cccc4C)cc3B3c4ccc5oc6cc7c(cc6c5c4N(c4ccc(C(C)(C)C)cc4-c4ccccc4)c4cc(N(c5cccc(-c6ccccc6)c5)c5cccc(C(C)(C)C)c5)cc1c43)C(C)(C)CCC7(C)C)C(C)(C)CCC2(C)C ; Cc1cc(C)c(-c2ccc3c(c2)B2c4ccc5oc6cc7c(cc6c5c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)C(C)(C)CCC7(C)C)c(C)c1]

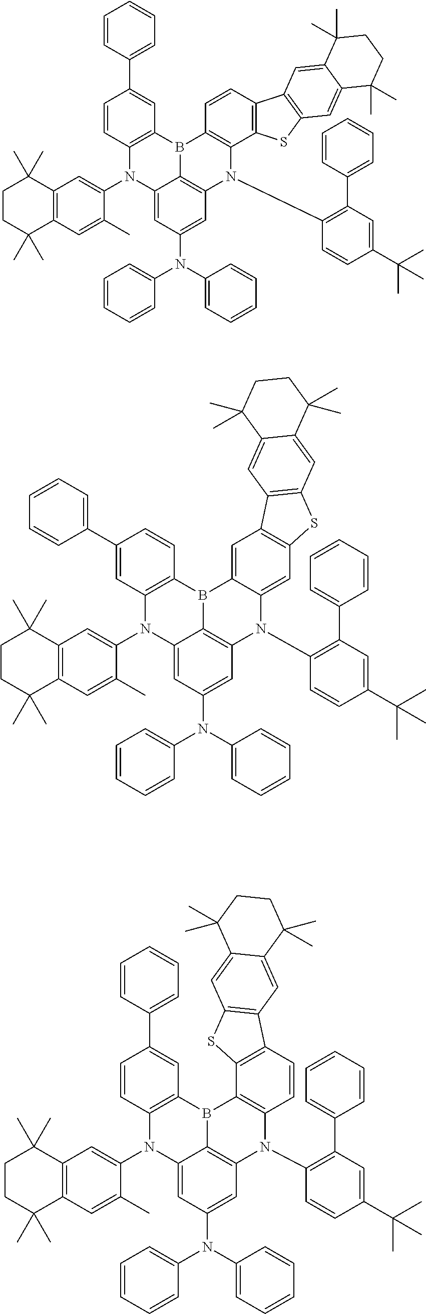 [SMILES: Cc1cc2c(cc1N1c3ccc(-c4ccccc4)cc3B3c4ccc5c(sc6cc7c(cc65)C(C)(C)CCC7(C)C)c4N(c4ccc(C(C)(C)C)cc4-c4ccccc4)c4cc(N(c5ccccc5)c5ccccc5)cc1c43)C(C)(C)CCC2(C)C ; Cc1cc2c(cc1N1c3cc(-c4ccccc4)ccc3B3c4cc5c(cc4N(c4ccc(C(C)(C)C)cc4-c4ccccc4)c4cc(N(c6ccccc6)c6ccccc6)cc1c43)sc1cc3c(cc15)C(C)(C)CCC3(C)C)C(C)(C)CCC2(C)C ; Cc1cc2c(cc1N1c3ccc(-c4ccccc4)cc3B3c4c1cc(N(c1ccccc1)c1ccccc1)cc4N(c1ccc(C(C)(C)C)cc1-c1ccccc1)c1ccc4c(sc5cc6c(cc54)C(C)(C)CCC6(C)C)c13)C(C)(C)CCC2(C)C]

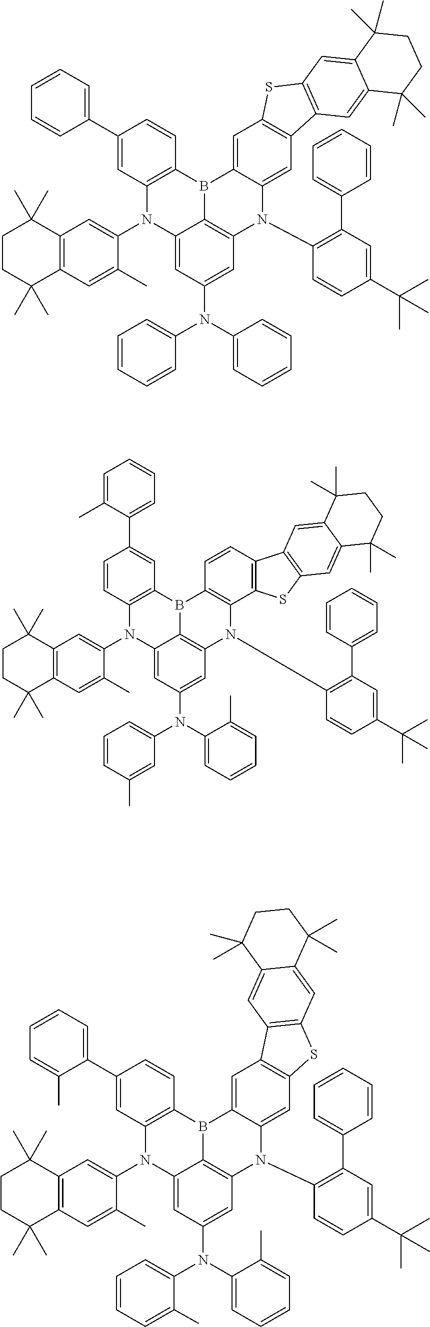 [SMILES: Cc1cc2c(cc1N1c3cc(-c4ccccc4)ccc3B3c4cc5sc6cc7c(cc6c5cc4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1cccc(N(c2cc3c4c(c2)N(c2ccc(C(C)(C)C)cc2-c2ccccc2)c2c(ccc5c2sc2cc6c(cc25)C(C)(C)CCC6(C)C)B4c2cc(-c4ccccc4C)ccc2N3c2cc3c(cc2C)C(C)(C)CCC3(C)C)c2ccccc2C)c1 ; Cc1ccccc1-c1ccc2c(c1)N(c1cc3c(cc1C)C(C)(C)CCC3(C)C)c1cc(N(c3ccccc3C)c3ccccc3C)cc3c1B2c1cc2c(cc1N3c1ccc(C(C)(C)C)cc1-c1ccccc1)sc1cc3c(cc12)C(C)(C)CCC3(C)C]

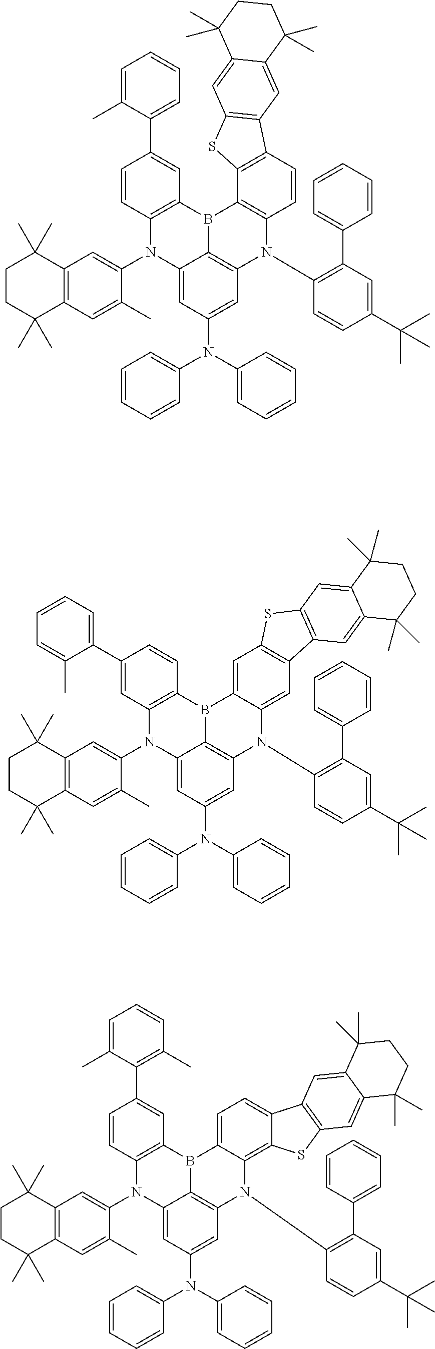 [SMILES: Cc1ccccc1-c1ccc2c(c1)B1c3c(cc(N(c4ccccc4)c4ccccc4)cc3N(c3ccc(C(C)(C)C)cc3-c3ccccc3)c3ccc4c(sc5cc6c(cc54)C(C)(C)CCC6(C)C)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2sc4cc5c(cc4c2cc1N3c1ccc(C(C)(C)C)cc1-c1ccccc1)C(C)(C)CCC5(C)C ; Cc1cc2c(cc1N1c3ccc(-c4c(C)cccc4C)cc3B3c4ccc5c(sc6cc7c(cc65)C(C)(C)CCC7(C)C)c4N(c4ccc(C(C)(C)C)cc4-c4ccccc4)c4cc(N(c5ccccc5)c5ccccc5)cc1c43)C(C)(C)CCC2(C)C]

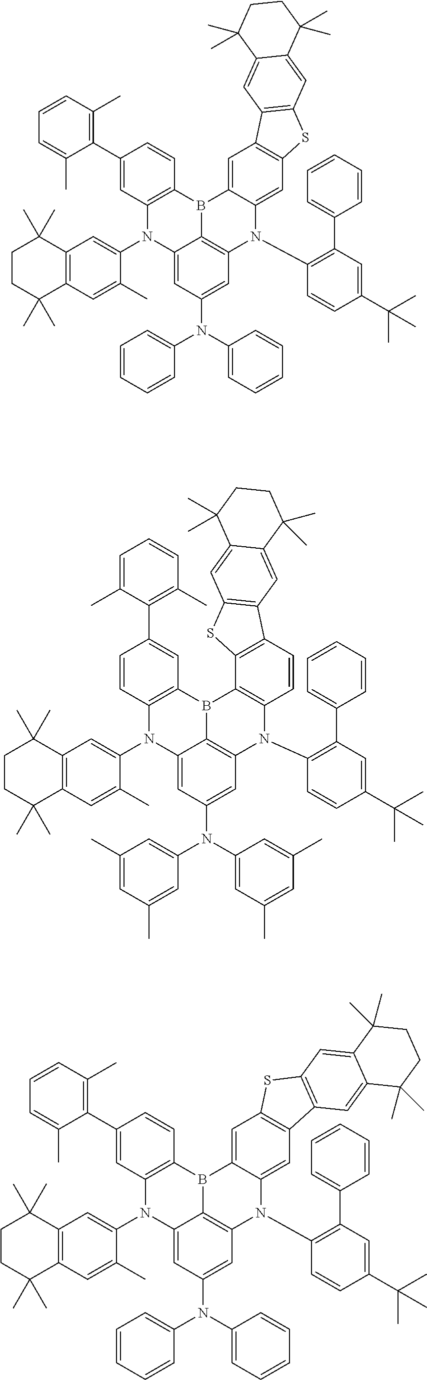 [SMILES: Cc1cc2c(cc1N1c3cc(-c4c(C)cccc4C)ccc3B3c4cc5c(cc4N(c4ccc(C(C)(C)C)cc4-c4ccccc4)c4cc(N(c6ccccc6)c6ccccc6)cc1c43)sc1cc3c(cc15)C(C)(C)CCC3(C)C)C(C)(C)CCC2(C)C ; Cc1cc(C)cc(N(c2cc(C)cc(C)c2)c2cc3c4c(c2)N(c2ccc(C(C)(C)C)cc2-c2ccccc2)c2ccc5c(sc6cc7c(cc65)C(C)(C)CCC7(C)C)c2B4c2cc(-c4c(C)cccc4C)ccc2N3c2cc3c(cc2C)C(C)(C)CCC3(C)C)c1 ; Cc1cc2c(cc1N1c3cc(-c4c(C)cccc4C)ccc3B3c4cc5sc6cc7c(cc6c5cc4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C]

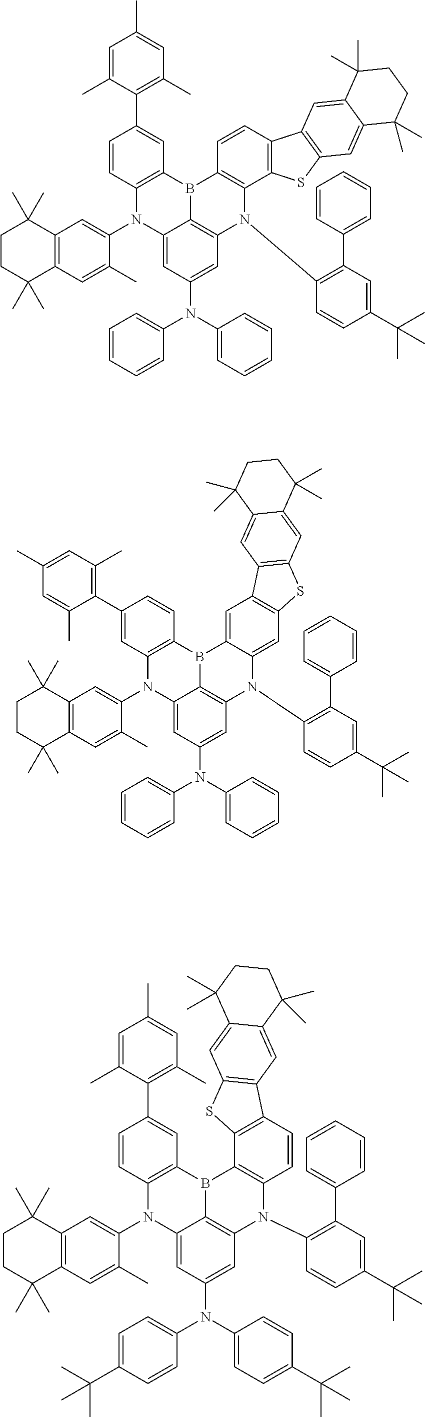

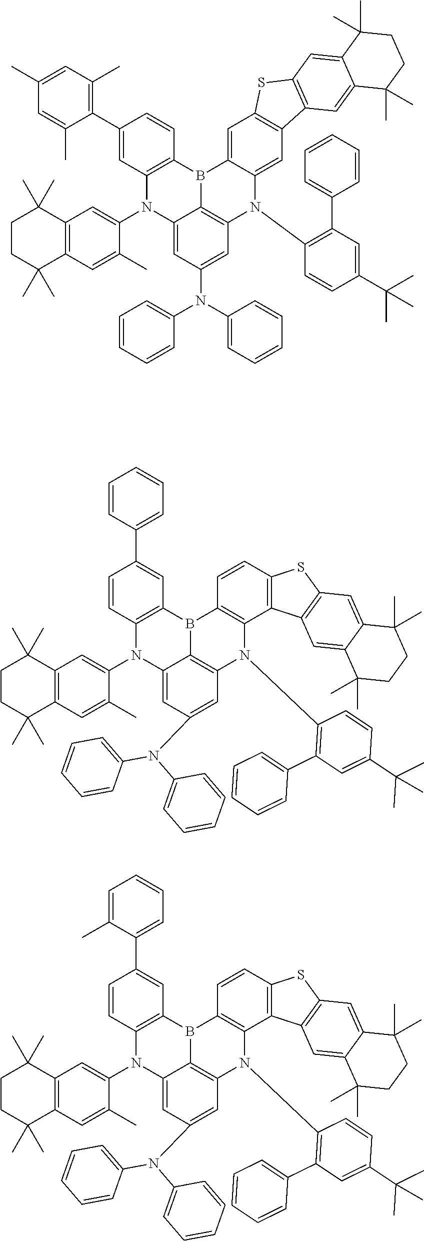 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3sc5cc6c(cc5c3cc2N4c2ccc(C(C)(C)C)cc2-c2ccccc2)C(C)(C)CCC6(C)C)c(C)c1 ; Cc1cc2c(cc1N1c3ccc(-c4ccccc4)cc3B3c4ccc5sc6cc7c(cc6c5c4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1ccccc1-c1ccc2c(c1)B1c3ccc4sc5cc6c(cc5c4c3N(c3ccc(C(C)(C)C)cc3-c3ccccc3)c3cc(N(c4ccccc4)c4ccccc4)cc(c31)N2c1cc2c(cc1C)C(C)(C)CCC2(C)C)C(C)(C)CCC6(C)C]

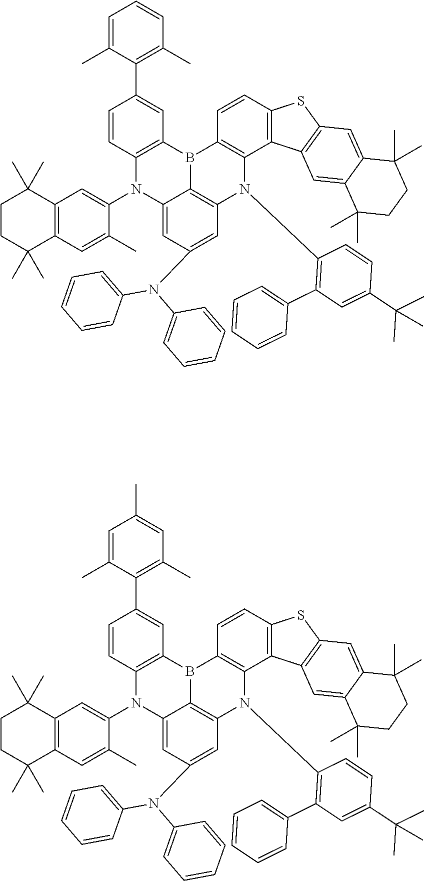 [SMILES: Cc1cc2c(cc1N1c3ccc(-c4c(C)cccc4C)cc3B3c4ccc5sc6cc7c(cc6c5c4N(c4ccc(C(C)(C)C)cc4-c4ccccc4)c4cc(N(c5ccccc5)c5ccccc5)cc1c43)C(C)(C)CCC7(C)C)C(C)(C)CCC2(C)C ; Cc1cc(C)c(-c2ccc3c(c2)B2c4ccc5sc6cc7c(cc6c5c4N(c4ccc(C(C)(C)C)cc4-c4ccccc4)c4cc(N(c5ccccc5)c5ccccc5)cc(c42)N3c2cc3c(cc2C)C(C)(C)CCC3(C)C)C(C)(C)CCC7(C)C)c(C)c1]

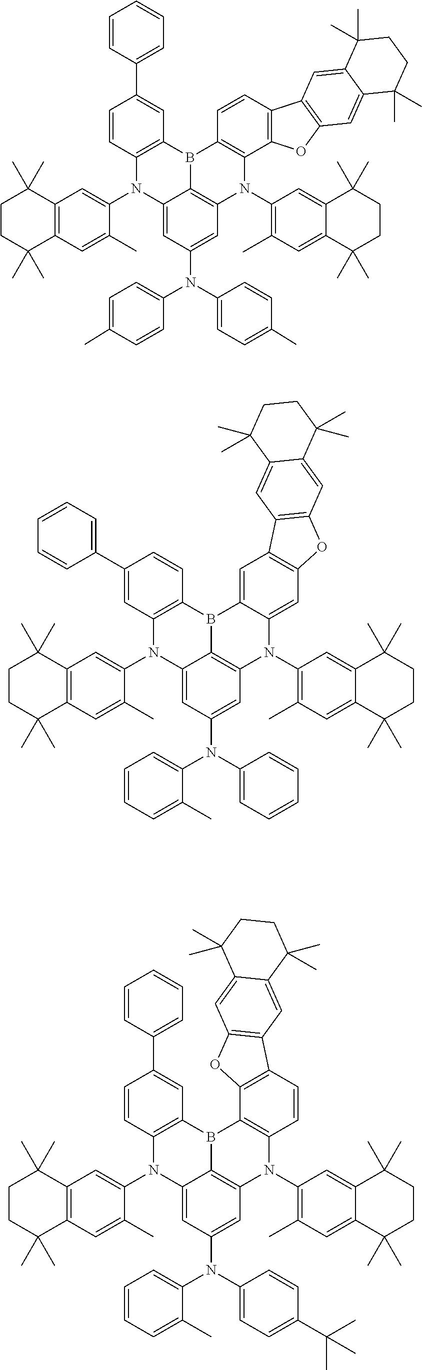 [SMILES: Cc1ccc(N(c2ccc(C)cc2)c2cc3c4c(c2)N(c2cc5c(cc2C)C(C)(C)CCC5(C)C)c2c(ccc5c2oc2cc6c(cc25)C(C)(C)CCC6(C)C)B4c2cc(-c4ccccc4)ccc2N3c2cc3c(cc2C)C(C)(C)CCC3(C)C)cc1 ; Cc1ccccc1N(c1ccccc1)c1cc2c3c(c1)N(c1cc4c(cc1C)C(C)(C)CCC4(C)C)c1cc4oc5cc6c(cc5c4cc1B3c1ccc(-c3ccccc3)cc1N2c1cc2c(cc1C)C(C)(C)CCC2(C)C)C(C)(C)CCC6(C)C ; Cc1ccccc1N(c1ccc(C(C)(C)C)cc1)c1cc2c3c(c1)N(c1cc4c(cc1C)C(C)(C)CCC4(C)C)c1ccc4c(oc5cc6c(cc54)C(C)(C)CCC6(C)C)c1B3c1cc(-c3ccccc3)ccc1N2c1cc2c(cc1C)C(C)(C)CCC2(C)C]

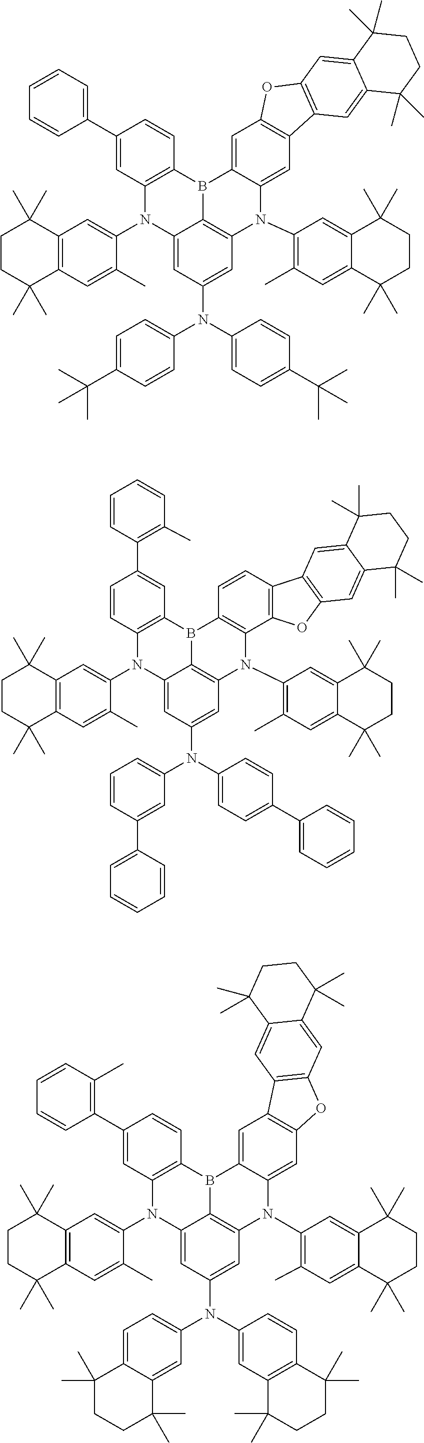

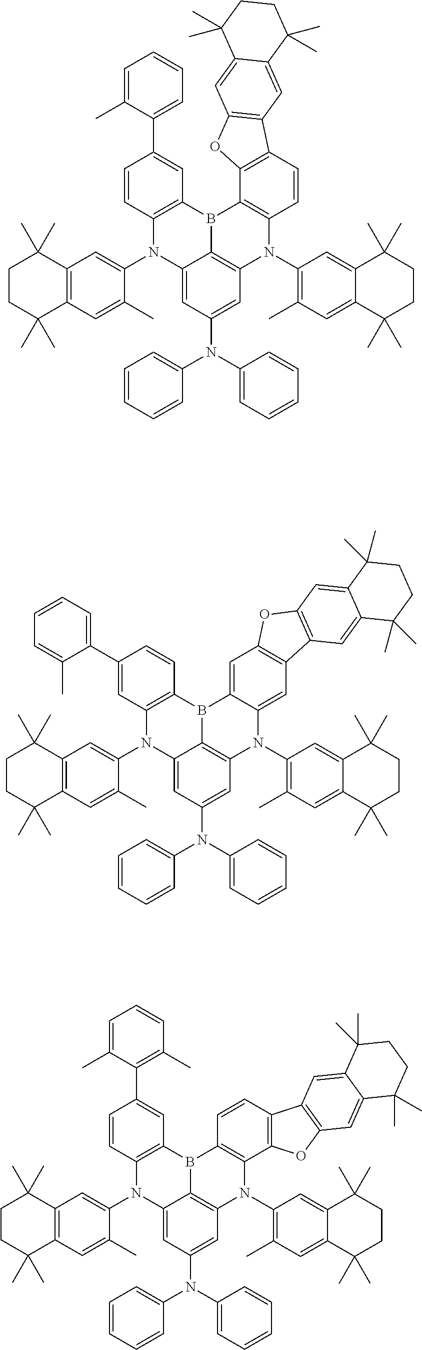 [SMILES: Cc1ccccc1-c1ccc2c(c1)B1c3c(cc(N(c4ccccc4)c4ccccc4)cc3N(c3cc4c(cc3C)C(C)(C)CCC4(C)C)c3ccc4c(oc5cc6c(cc54)C(C)(C)CCC6(C)C)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2oc4cc5c(cc4c2cc1N3c1cc2c(cc1C)C(C)(C)CCC2(C)C)C(C)(C)CCC5(C)C ; Cc1cc2c(cc1N1c3ccc(-c4c(C)cccc4C)cc3B3c4ccc5c(oc6cc7c(cc65)C(C)(C)CCC7(C)C)c4N(c4cc5c(cc4C)C(C)(C)CCC5(C)C)c4cc(N(c5ccccc5)c5ccccc5)cc1c43)C(C)(C)CCC2(C)C]

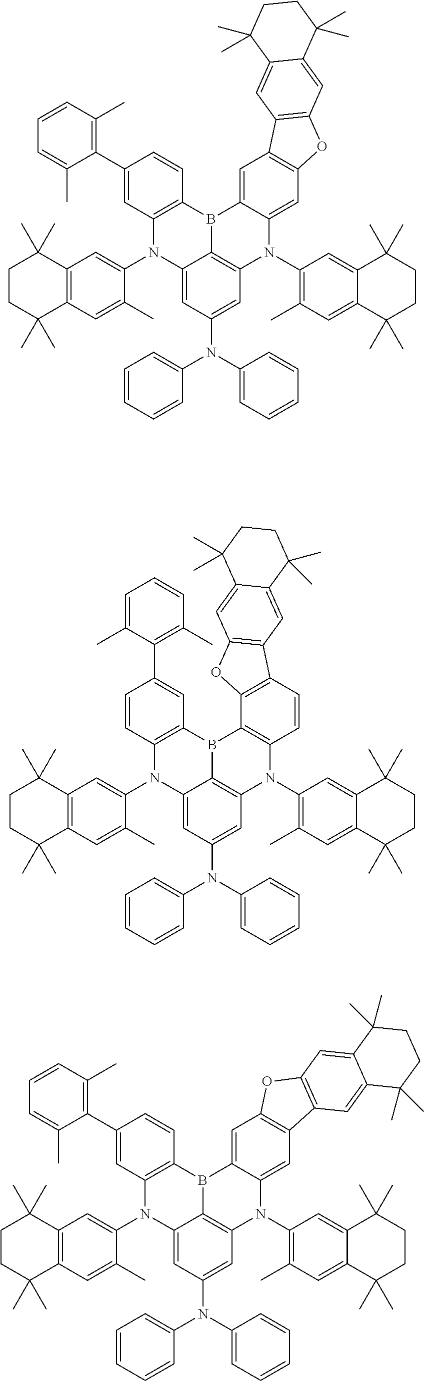 [SMILES: Cc1cc2c(cc1N1c3cc(-c4c(C)cccc4C)ccc3B3c4cc5c(cc4N(c4cc6c(cc4C)C(C)(C)CCC6(C)C)c4cc(N(c6ccccc6)c6ccccc6)cc1c43)oc1cc3c(cc15)C(C)(C)CCC3(C)C)C(C)(C)CCC2(C)C ; Cc1cc2c(cc1N1c3ccc(-c4c(C)cccc4C)cc3B3c4c1cc(N(c1ccccc1)c1ccccc1)cc4N(c1cc4c(cc1C)C(C)(C)CCC4(C)C)c1ccc4c(oc5cc6c(cc54)C(C)(C)CCC6(C)C)c13)C(C)(C)CCC2(C)C ; Cc1cc2c(cc1N1c3cc(-c4c(C)cccc4C)ccc3B3c4cc5oc6cc7c(cc6c5cc4N(c4cc5c(cc4C)C(C)(C)CCC5(C)C)c4cc(N(c5ccccc5)c5ccccc5)cc1c43)C(C)(C)CCC7(C)C)C(C)(C)CCC2(C)C]

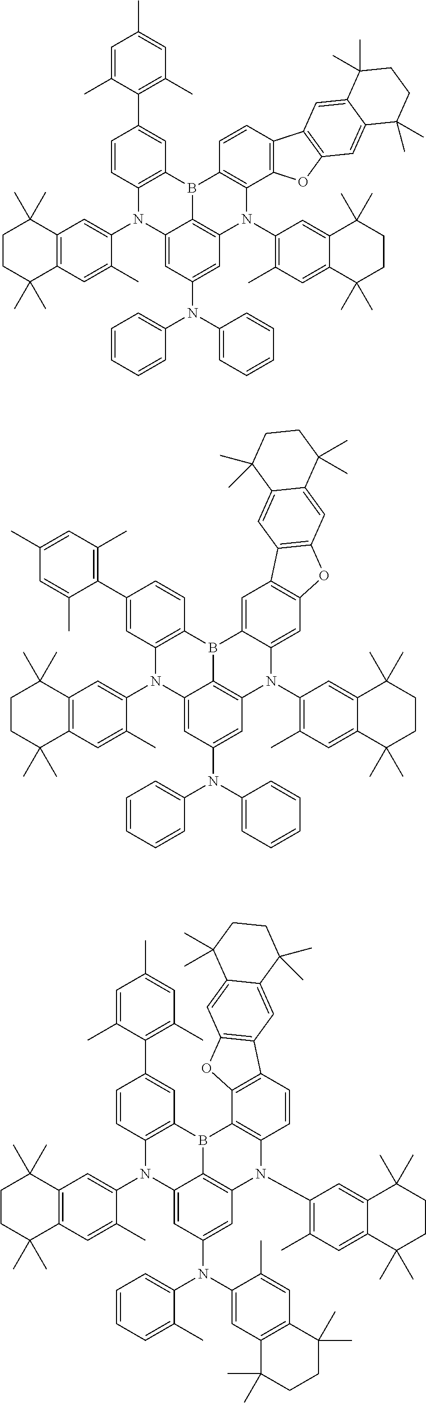

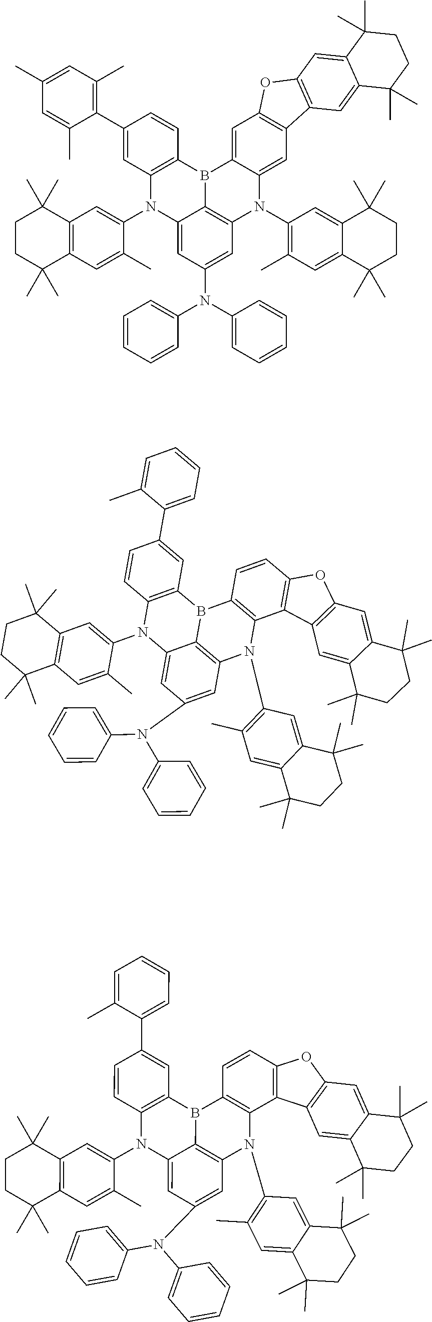 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3oc5cc6c(cc5c3cc2N4c2cc3c(cc2C)C(C)(C)CCC3(C)C)C(C)(C)CCC6(C)C)c(C)c1 ; Cc1ccccc1-c1ccc2c(c1)B1c3ccc4oc5cc6c(cc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C)C(C)(C)CCC6(C)C ; Cc1ccccc1-c1ccc2c(c1)B1c3ccc4oc5cc6c(cc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C)C(C)(C)CCC6(C)C]

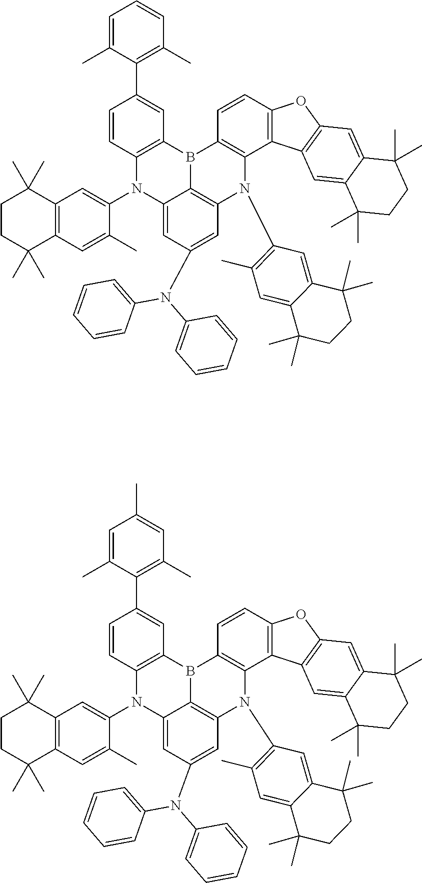 [SMILES: Cc1cc2c(cc1N1c3ccc(-c4c(C)cccc4C)cc3B3c4ccc5oc6cc7c(cc6c5c4N(c4cc5c(cc4C)C(C)(C)CCC5(C)C)c4cc(N(c5ccccc5)c5ccccc5)cc1c43)C(C)(C)CCC7(C)C)C(C)(C)CCC2(C)C ; Cc1cc(C)c(-c2ccc3c(c2)B2c4ccc5oc6cc7c(cc6c5c4N(c4cc5c(cc4C)C(C)(C)CCC5(C)C)c4cc(N(c5ccccc5)c5ccccc5)cc(c42)N3c2cc3c(cc2C)C(C)(C)CCC3(C)C)C(C)(C)CCC7(C)C)c(C)c1]

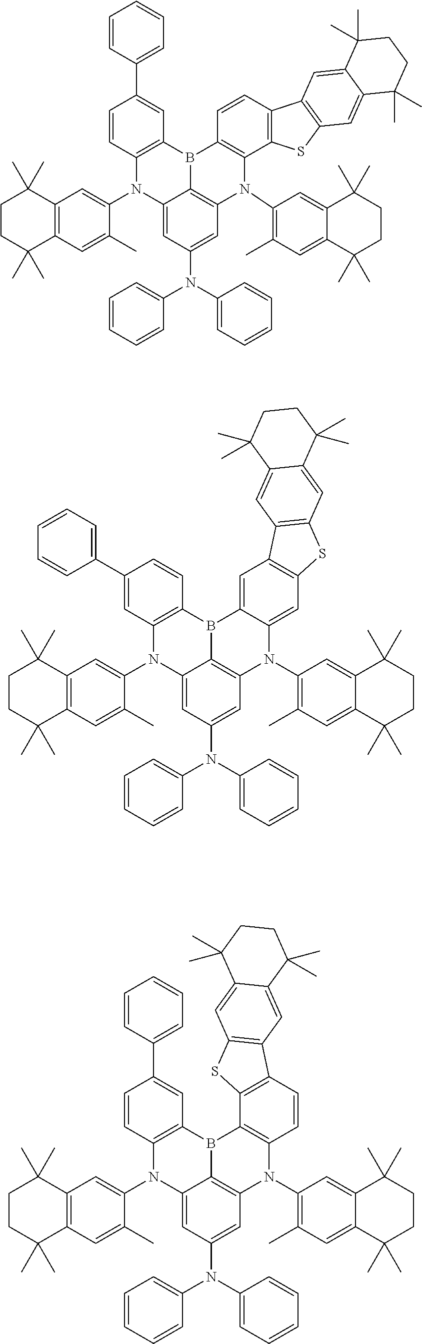 [SMILES: Cc1cc2c(cc1N1c3ccc(-c4ccccc4)cc3B3c4ccc5c(sc6cc7c(cc65)C(C)(C)CCC7(C)C)c4N(c4cc5c(cc4C)C(C)(C)CCC5(C)C)c4cc(N(c5ccccc5)c5ccccc5)cc1c43)C(C)(C)CCC2(C)C ; Cc1cc2c(cc1N1c3cc(-c4ccccc4)ccc3B3c4cc5c(cc4N(c4cc6c(cc4C)C(C)(C)CCC6(C)C)c4cc(N(c6ccccc6)c6ccccc6)cc1c43)sc1cc3c(cc15)C(C)(C)CCC3(C)C)C(C)(C)CCC2(C)C ; Cc1cc2c(cc1N1c3ccc(-c4ccccc4)cc3B3c4c1cc(N(c1ccccc1)c1ccccc1)cc4N(c1cc4c(cc1C)C(C)(C)CCC4(C)C)c1ccc4c(sc5cc6c(cc54)C(C)(C)CCC6(C)C)c13)C(C)(C)CCC2(C)C]

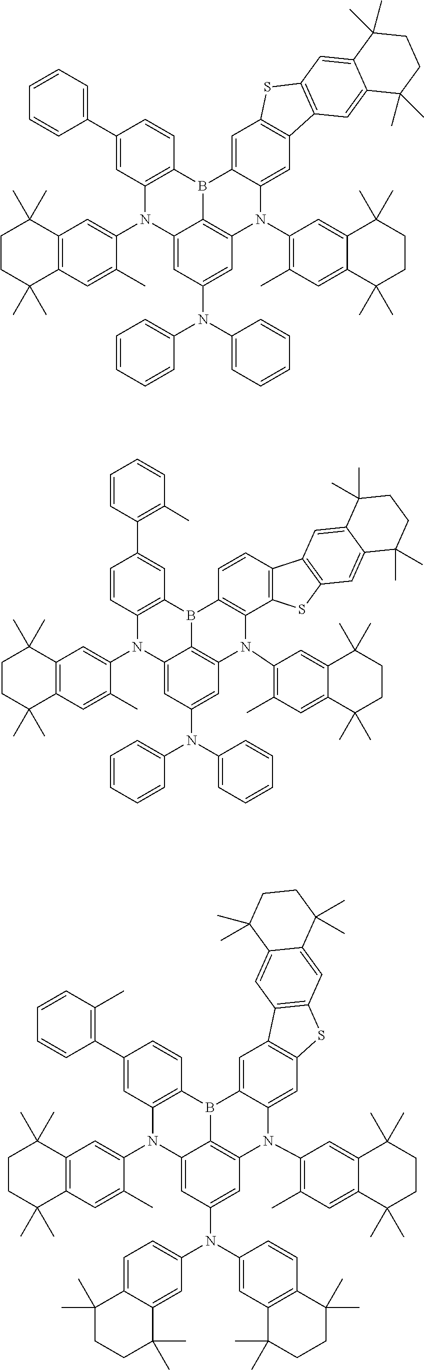 [SMILES: Cc1cc2c(cc1N1c3cc(-c4ccccc4)ccc3B3c4cc5sc6cc7c(cc6c5cc4N(c4cc5c(cc4C)C(C)(C)CCC5(C)C)c4cc(N(c5ccccc5)c5ccccc5)cc1c43)C(C)(C)CCC7(C)C)C(C)(C)CCC2(C)C ; Cc1ccccc1-c1ccc2c(c1)B1c3ccc4c(sc5cc6c(cc54)C(C)(C)CCC6(C)C)c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccc4c(c3)C(C)(C)CCC4(C)C)c3ccc4c(c3)C(C)(C)CCC4(C)C)cc3c1B2c1cc2c(cc1N3c1cc3c(cc1C)C(C)(C)CCC3(C)C)sc1cc3c(cc12)C(C)(C)CCC3(C)C]

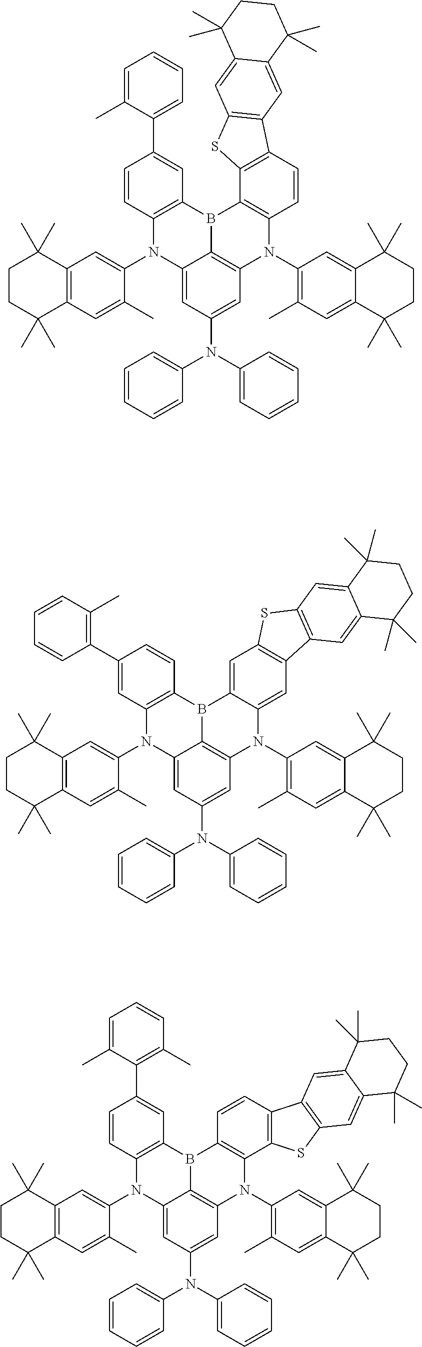 [SMILES: Cc1ccccc1-c1ccc2c(c1)B1c3c(cc(N(c4ccccc4)c4ccccc4)cc3N(c3cc4c(cc3C)C(C)(C)CCC4(C)C)c3ccc4c(sc5cc6c(cc54)C(C)(C)CCC6(C)C)c31)N2c1cc2c(cc1C)C(C)(C)CCC2(C)C ; Cc1ccccc1-c1ccc2c(c1)N(c1cc3c(cc1C)C(C)(C)CCC3(C)C)c1cc(N(c3ccccc3)c3ccccc3)cc3c1B2c1cc2sc4cc5c(cc4c2cc1N3c1cc2c(cc1C)C(C)(C)CCC2(C)C)C(C)(C)CCC5(C)C ; Cc1cc2c(cc1N1c3ccc(-c4c(C)cccc4C)cc3B3c4ccc5c(sc6cc7c(cc65)C(C)(C)CCC7(C)C)c4N(c4cc5c(cc4C)C(C)(C)CCC5(C)C)c4cc(N(c5ccccc5)c5ccccc5)cc1c43)C(C)(C)CCC2(C)C]

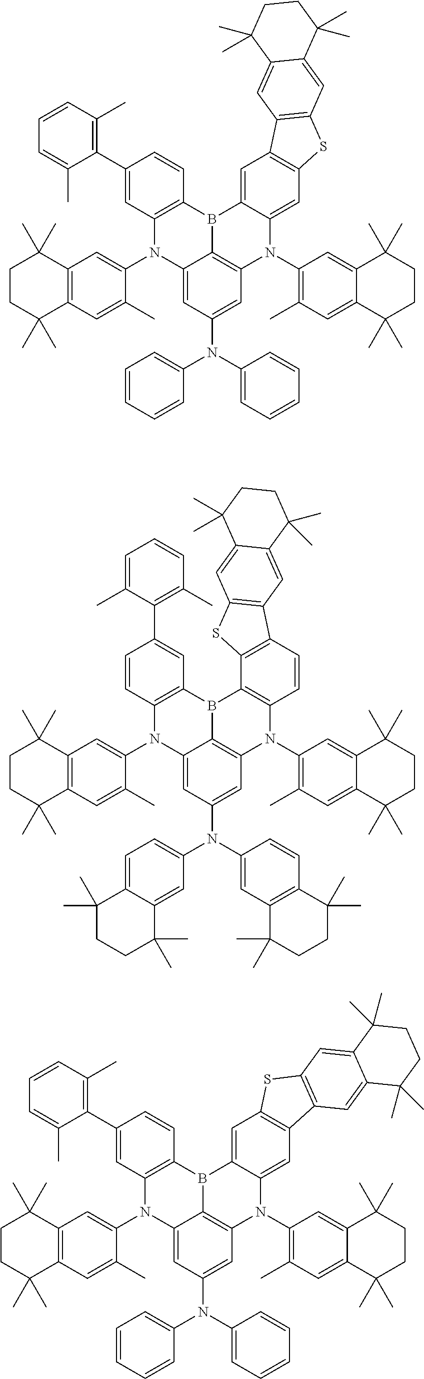

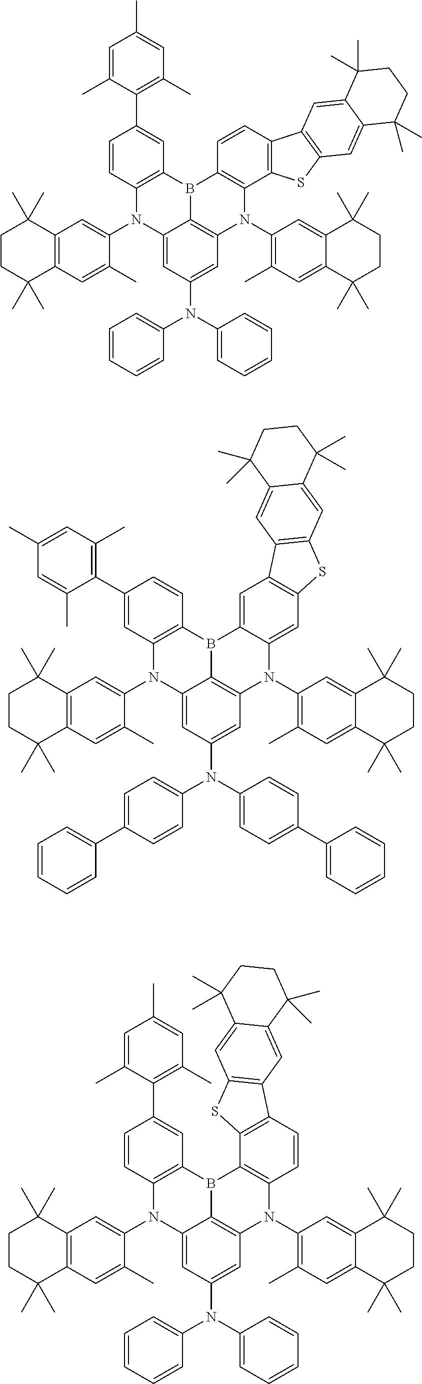

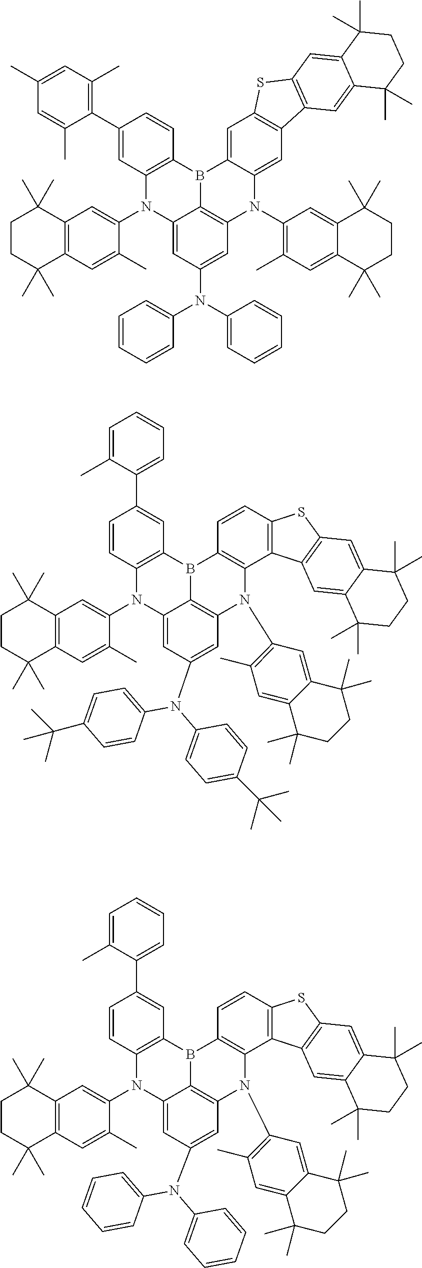 [SMILES: Cc1cc(C)c(-c2ccc3c(c2)N(c2cc4c(cc2C)C(C)(C)CCC4(C)C)c2cc(N(c4ccccc4)c4ccccc4)cc4c2B3c2cc3sc5cc6c(cc5c3cc2N4c2cc3c(cc2C)C(C)(C)CCC3(C)C)C(C)(C)CCC6(C)C)c(C)c1 ; Cc1ccccc1-c1ccc2c(c1)B1c3ccc4sc5cc6c(cc5c4c3N(c3cc4c(cc3C)C(C)(C)CCC4(C)C)c3cc(N(c4ccc(C(C)(C)C)cc4)c4ccc(C(C)(C)C)cc4)cc(c31)N2c1cc2c(cc1C)C(C)(C)CCC2(C)C)C(C)(C)CCC6(C)C ; Cc1ccccc1-c1ccc2c(c1)B1c3ccc4sc5cc6c(cc5c4c3N(c3cc4c(cc3C)C(C)(C)CCC4(C)C)c3cc(N(c4ccccc4)c4ccccc4)cc(c31)N2c1cc2c(cc1C)C(C)(C)CCC2(C)C)C(C)(C)CCC6(C)C]

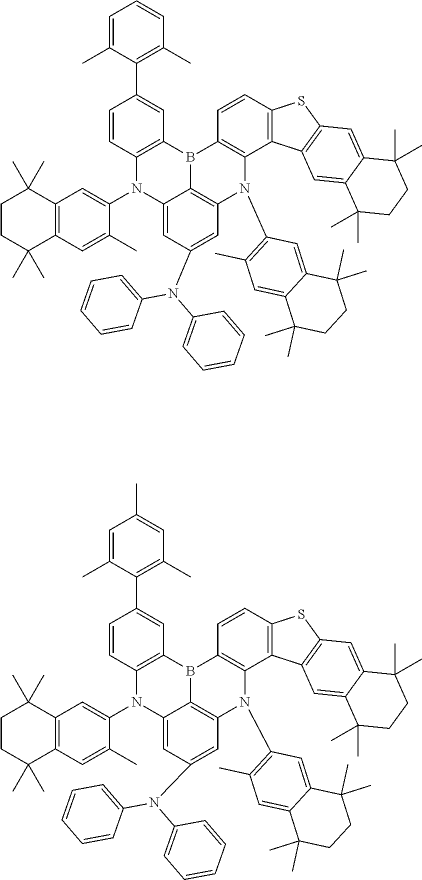 [SMILES: Cc1cc2c(cc1N1c3ccc(-c4c(C)cccc4C)cc3B3c4ccc5sc6cc7c(cc6c5c4N(c4cc5c(cc4C)C(C)(C)CCC5(C)C)c4cc(N(c5ccccc5)c5ccccc5)cc1c43)C(C)(C)CCC7(C)C)C(C)(C)CCC2(C)C ; Cc1cc(C)c(-c2ccc3c(c2)B2c4ccc5sc6cc7c(cc6c5c4N(c4cc5c(cc4C)C(C)(C)CCC5(C)C)c4cc(N(c5ccccc5)c5ccccc5)cc(c42)N3c2cc3c(cc2C)C(C)(C)CCC3(C)C)C(C)(C)CCC7(C)C)c(C)c1]

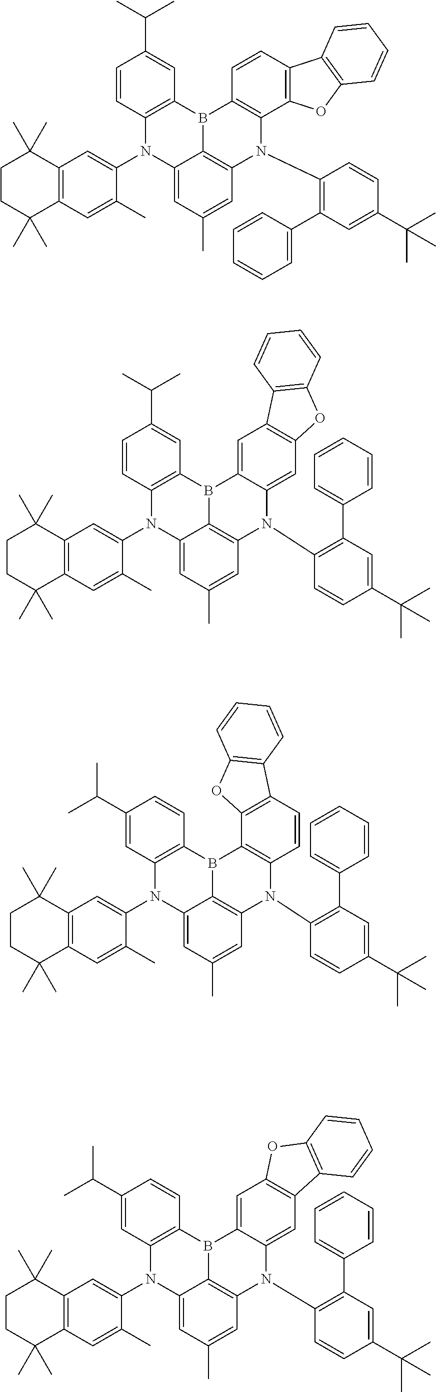 [SMILES: Cc1cc2c3c(c1)N(c1ccc(C(C)(C)C)cc1-c1ccccc1)c1c(ccc4c1oc1ccccc14)B3c1cc(C(C)C)ccc1N2c1cc2c(cc1C)C(C)(C)CCC2(C)C ; Cc1cc2c3c(c1)N(c1ccc(C(C)(C)C)cc1-c1ccccc1)c1cc4oc5ccccc5c4cc1B3c1cc(C(C)C)ccc1N2c1cc2c(cc1C)C(C)(C)CCC2(C)C ; Cc1cc2c3c(c1)N(c1ccc(C(C)(C)C)cc1-c1ccccc1)c1ccc4c(oc5ccccc54)c1B3c1ccc(C(C)C)cc1N2c1cc2c(cc1C)C(C)(C)CCC2(C)C ; Cc1cc2c3c(c1)N(c1ccc(C(C)(C)C)cc1-c1ccccc1)c1cc4c(cc1B3c1ccc(C(C)C)cc1N2c1cc2c(cc1C)C(C)(C)CCC2(C)C)oc1ccccc14]

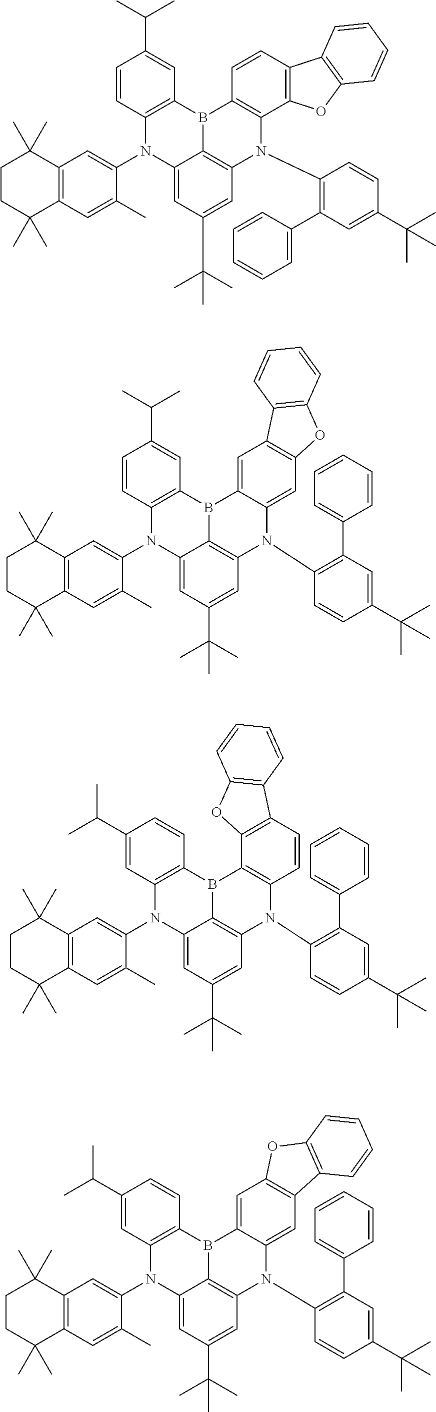 [SMILES: Cc1cc2c(cc1N1c3ccc(C(C)C)cc3B3c4ccc5c(oc6ccccc65)c4N(c4ccc(C(C)(C)C)cc4-c4ccccc4)c4cc(C(C)(C)C)cc1c43)C(C)(C)CCC2(C)C ; Cc1cc2c(cc1N1c3ccc(C(C)C)cc3B3c4cc5c(cc4N(c4ccc(C(C)(C)C)cc4-c4ccccc4)c4cc(C(C)(C)C)cc1c43)oc1ccccc15)C(C)(C)CCC2(C)C ; Cc1cc2c(cc1N1c3cc(C(C)C)ccc3B3c4c1cc(C(C)(C)C)cc4N(c1ccc(C(C)(C)C)cc1-c1ccccc1)c1ccc4c(oc5ccccc54)c13)C(C)(C)CCC2(C)C ; Cc1cc2c(cc1N1c3cc(C(C)C)ccc3B3c4cc5oc6ccccc6c5cc4N(c4ccc(C(C)(C)C)cc4-c4ccccc4)c4cc(C(C)(C)C)cc1c43)C(C)(C)CCC2(C)C]

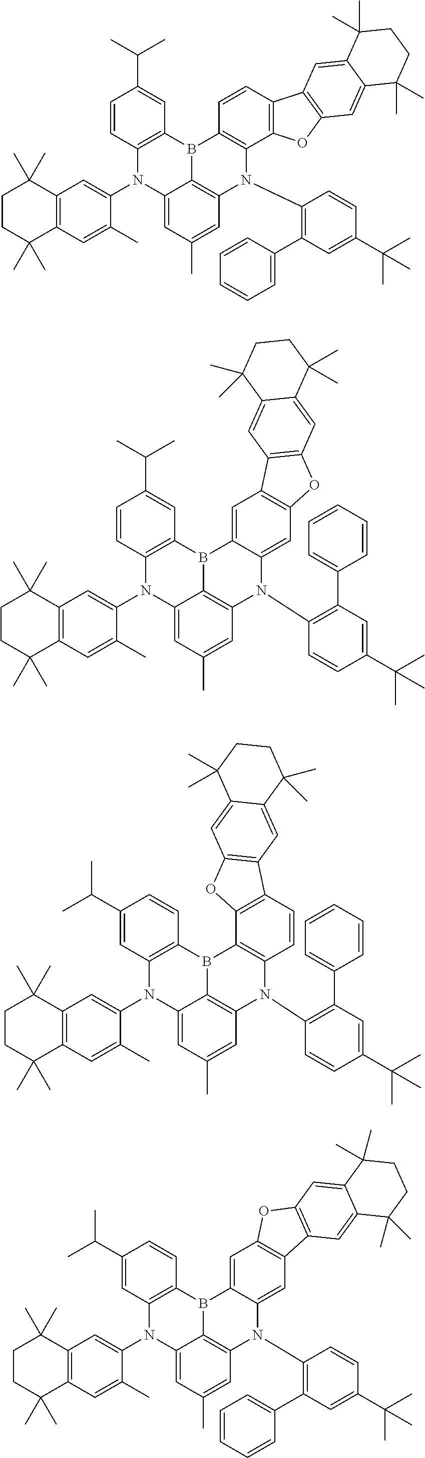

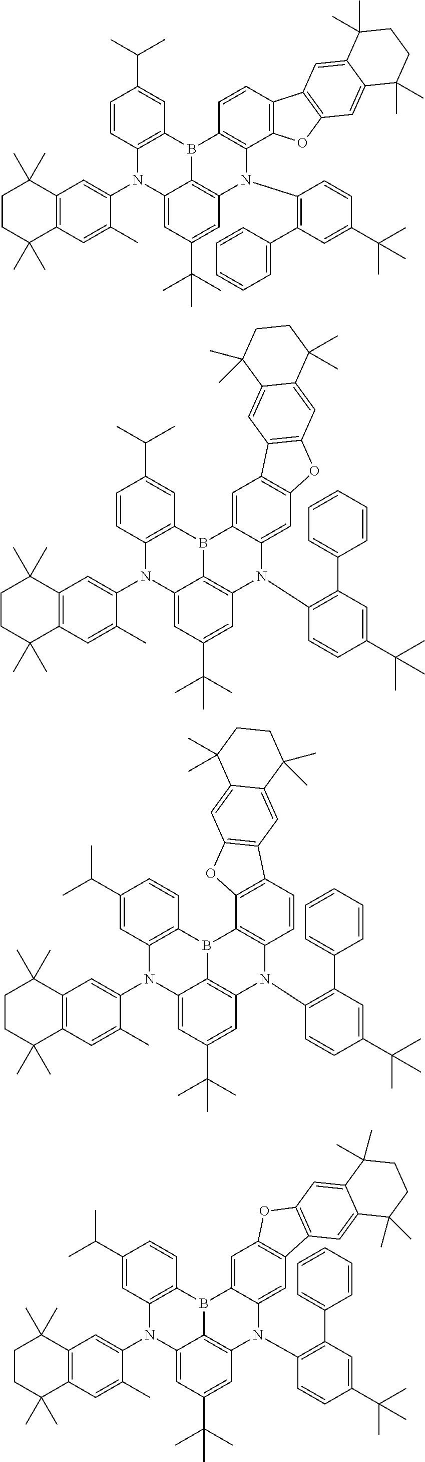

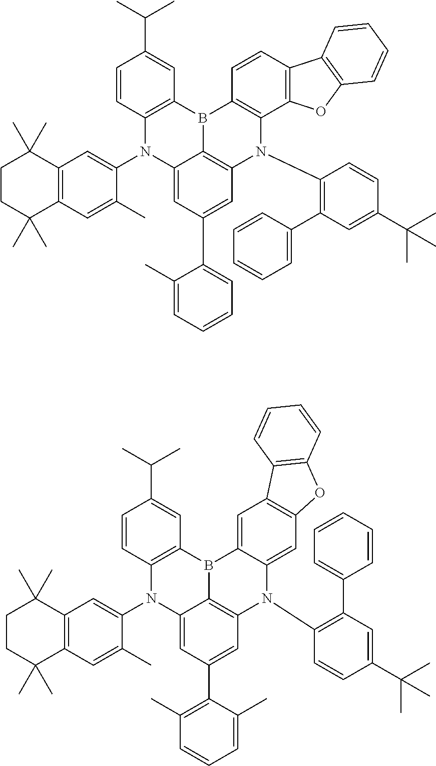 [SMILES: Cc1ccccc1-c1cc2c3c(c1)N(c1ccc(C(C)(C)C)cc1-c1ccccc1)c1c(ccc4c1oc1ccccc14)B3c1cc(C(C)C)ccc1N2c1cc2c(cc1C)C(C)(C)CCC2(C)C ; Cc1cc2c(cc1N1c3ccc(C(C)C)cc3B3c4cc5c(cc4N(c4ccc(C(C)(C)C)cc4-c4ccccc4)c4cc(-c6c(C)cccc6C)cc1c43)oc1ccccc15)C(C)(C)CCC2(C)C]

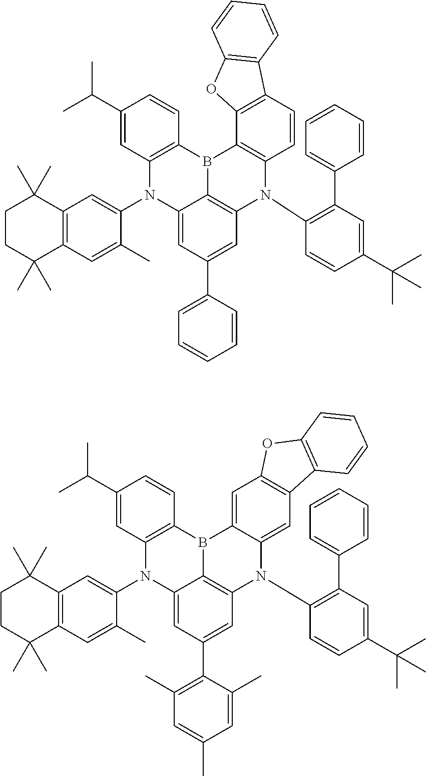 [SMILES: Cc1cc2c(cc1N1c3cc(C(C)C)ccc3B3c4c1cc(-c1ccccc1)cc4N(c1ccc(C(C)(C)C)cc1-c1ccccc1)c1ccc4c(oc5ccccc54)c13)C(C)(C)CCC2(C)C ; Cc1cc(C)c(-c2cc3c4c(c2)N(c2ccc(C(C)(C)C)cc2-c2ccccc2)c2cc5c(cc2B4c2ccc(C(C)C)cc2N3c2cc3c(cc2C)C(C)(C)CCC3(C)C)oc2ccccc25)c(C)c1]

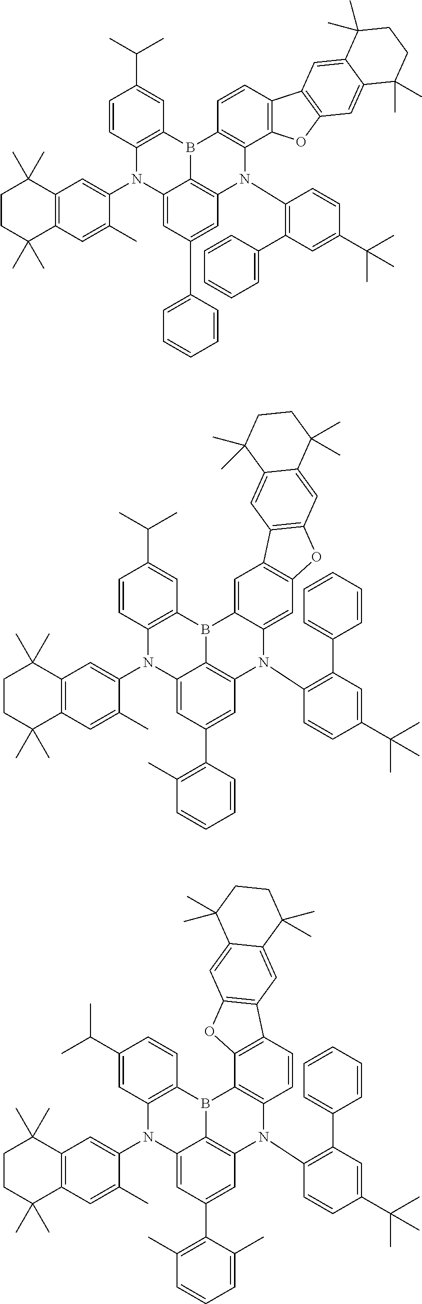 [SMILES: Cc1cc2c(cc1N1c3ccc(C(C)C)cc3B3c4ccc5c(oc6cc7c(cc65)C(C)(C)CCC7(C)C)c4N(c4ccc(C(C)(C)C)cc4-c4ccccc4)c4cc(-c5ccccc5)cc1c43)C(C)(C)CCC2(C)C ; Cc1ccccc1-c1cc2c3c(c1)N(c1ccc(C(C)(C)C)cc1-c1ccccc1)c1cc4oc5cc6c(cc5c4cc1B3c1cc(C(C)C)ccc1N2c1cc2c(cc1C)C(C)(C)CCC2(C)C)C(C)(C)CCC6(C)C ; Cc1cc2c(cc1N1c3cc(C(C)C)ccc3B3c4c1cc(-c1c(C)cccc1C)cc4N(c1ccc(C(C)(C)C)cc1-c1ccccc1)c1ccc4c(oc5cc6c(cc54)C(C)(C)CCC6(C)C)c13)C(C)(C)CCC2(C)C]

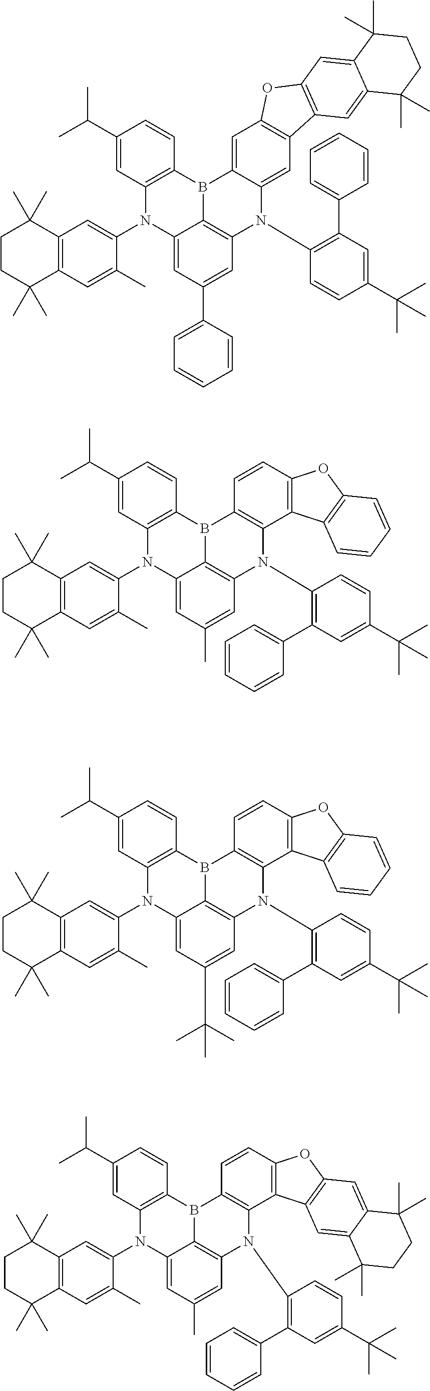 [SMILES: Cc1cc2c(cc1N1c3cc(C(C)C)ccc3B3c4cc5oc6cc7c(cc6c5cc4N(c4ccc(C(C)(C)C)cc4-c4ccccc4)c4cc(-c5ccccc5)cc1c43)C(C)(C)CCC7(C)C)C(C)(C)CCC2(C)C ; Cc1cc2c3c(c1)N(c1ccc(C(C)(C)C)cc1-c1ccccc1)c1c(ccc4oc5ccccc5c14)B3c1ccc(C(C)C)cc1N2c1cc2c(cc1C)C(C)(C)CCC2(C)C ; Cc1cc2c(cc1N1c3cc(C(C)C)ccc3B3c4ccc5oc6ccccc6c5c4N(c4ccc(C(C)(C)C)cc4-c4ccccc4)c4cc(C(C)(C)C)cc1c43)C(C)(C)CCC2(C)C ; Cc1cc2c3c(c1)N(c1ccc(C(C)(C)C)cc1-c1ccccc1)c1c(ccc4oc5cc6c(cc5c14)C(C)(C)CCC6(C)C)B3c1ccc(C(C)C)cc1N2c1cc2c(cc1C)C(C)(C)CCC2(C)C]

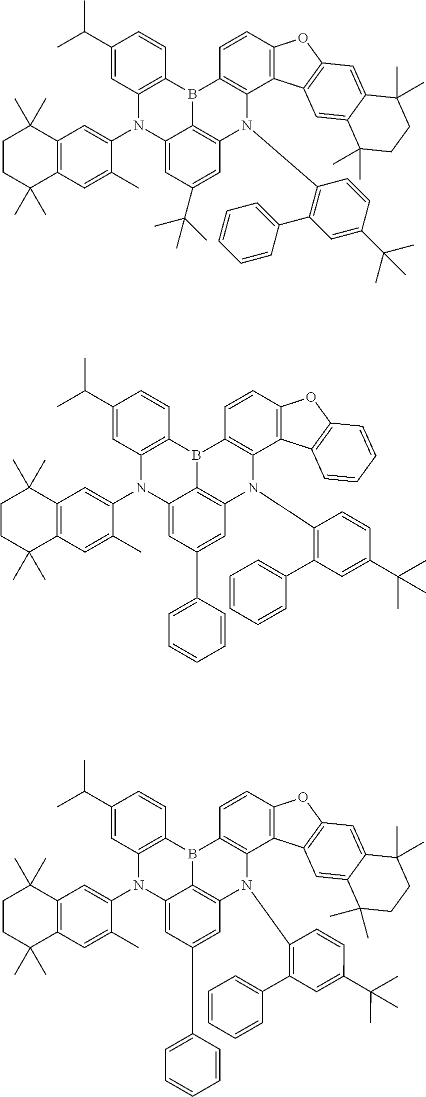 [SMILES: Cc1cc2c(cc1N1c3cc(C(C)C)ccc3B3c4ccc5oc6cc7c(cc6c5c4N(c4ccc(C(C)(C)C)cc4-c4ccccc4)c4cc(C(C)(C)C)cc1c43)C(C)(C)CCC7(C)C)C(C)(C)CCC2(C)C ; Cc1cc2c(cc1N1c3cc(C(C)C)ccc3B3c4ccc5oc6ccccc6c5c4N(c4ccc(C(C)(C)C)cc4-c4ccccc4)c4cc(-c5ccccc5)cc1c43)C(C)(C)CCC2(C)C ; Cc1cc2c(cc1N1c3cc(C(C)C)ccc3B3c4ccc5oc6cc7c(cc6c5c4N(c4ccc(C(C)(C)C)cc4-c4ccccc4)c4cc(-c5ccccc5)cc1c43)C(C)(C)CCC7(C)C)C(C)(C)CCC2(C)C]

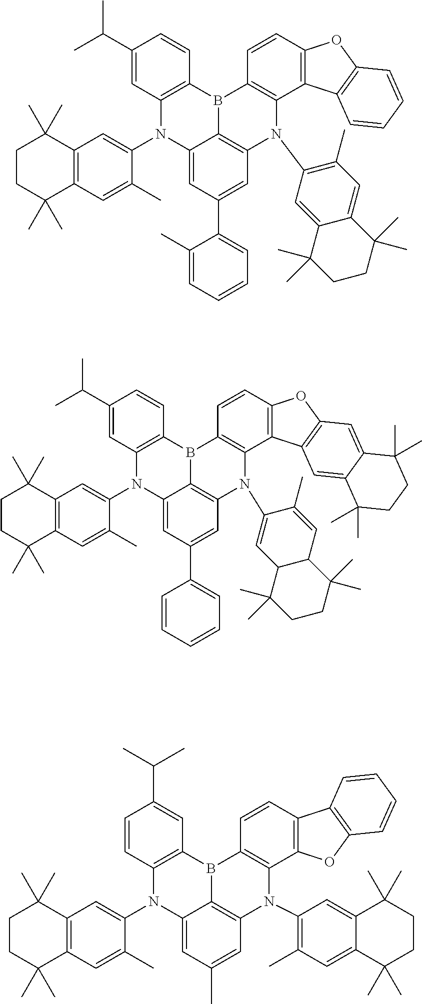 [SMILES: Cc1ccccc1-c1cc2c3c(c1)N(c1cc4c(cc1C)C(C)(C)CCC4(C)C)c1c(ccc4oc5ccccc5c14)B3c1ccc(C(C)C)cc1N2c1cc2c(cc1C)C(C)(C)CCC2(C)C ; CC1=CC2C(C=C1N1c3cc(-c4ccccc4)cc4c3B(c3ccc(C(C)C)cc3N4c3cc4c(cc3C)C(C)(C)CCC4(C)C)c3ccc4oc5cc6c(cc5c4c31)C(C)(C)CCC6(C)C)C(C)(C)CCC2(C)C ; Cc1cc2c3c(c1)N(c1cc4c(cc1C)C(C)(C)CCC4(C)C)c1c(ccc4c1oc1ccccc14)B3c1cc(C(C)C)ccc1N2c1cc2c(cc1C)C(C)(C)CCC2(C)C]

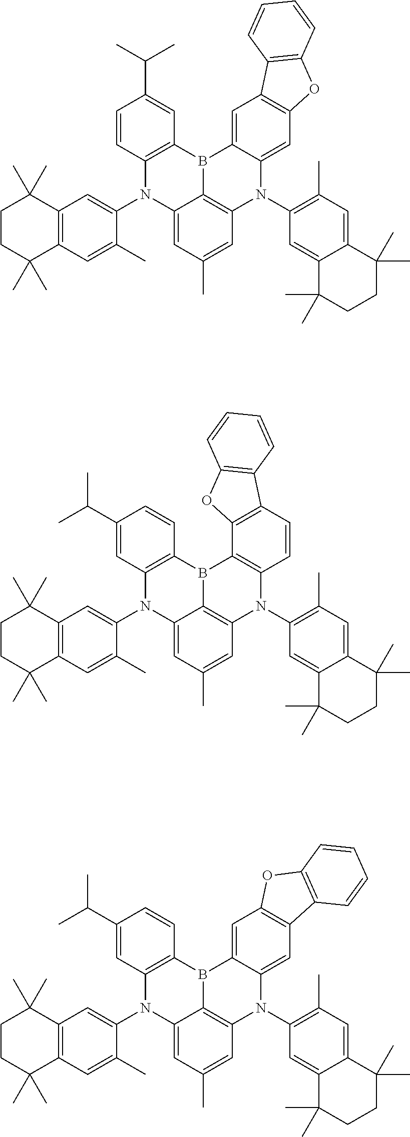 [SMILES: Cc1cc2c3c(c1)N(c1cc4c(cc1C)C(C)(C)CCC4(C)C)c1cc4oc5ccccc5c4cc1B3c1cc(C(C)C)ccc1N2c1cc2c(cc1C)C(C)(C)CCC2(C)C ; Cc1cc2c3c(c1)N(c1cc4c(cc1C)C(C)(C)CCC4(C)C)c1ccc4c(oc5ccccc54)c1B3c1ccc(C(C)C)cc1N2c1cc2c(cc1C)C(C)(C)CCC2(C)C ; Cc1cc2c3c(c1)N(c1cc4c(cc1C)C(C)(C)CCC4(C)C)c1cc4c(cc1B3c1ccc(C(C)C)cc1N2c1cc2c(cc1C)C(C)(C)CCC2(C)C)oc1ccccc14]

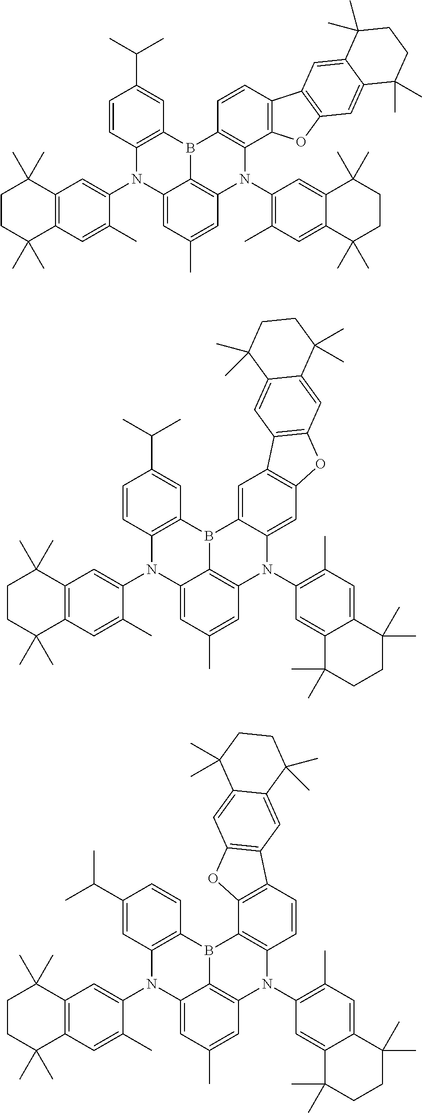 [SMILES: Cc1cc2c3c(c1)N(c1cc4c(cc1C)C(C)(C)CCC4(C)C)c1c(ccc4c1oc1cc5c(cc14)C(C)(C)CCC5(C)C)B3c1cc(C(C)C)ccc1N2c1cc2c(cc1C)C(C)(C)CCC2(C)C ; Cc1cc2c3c(c1)N(c1cc4c(cc1C)C(C)(C)CCC4(C)C)c1cc4oc5cc6c(cc5c4cc1B3c1cc(C(C)C)ccc1N2c1cc2c(cc1C)C(C)(C)CCC2(C)C)C(C)(C)CCC6(C)C ; Cc1cc2c3c(c1)N(c1cc4c(cc1C)C(C)(C)CCC4(C)C)c1ccc4c(oc5cc6c(cc54)C(C)(C)CCC6(C)C)c1B3c1ccc(C(C)C)cc1N2c1cc2c(cc1C)C(C)(C)CCC2(C)C]

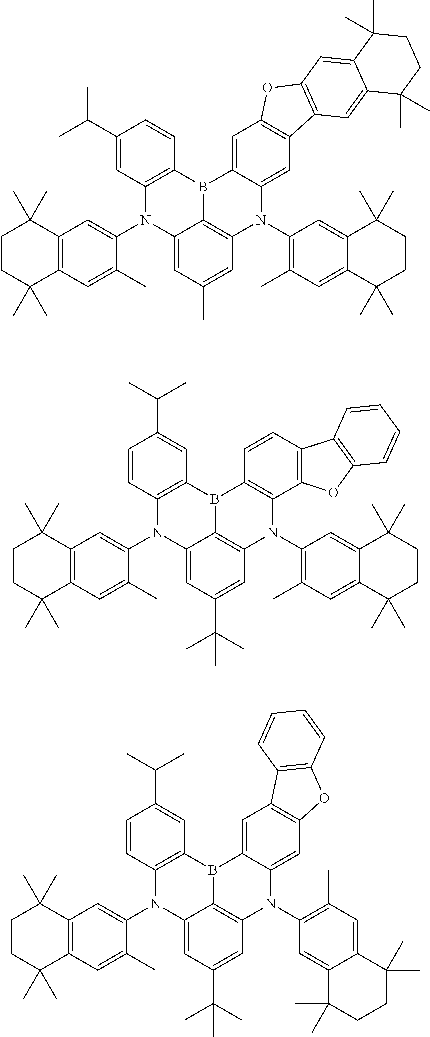 [SMILES: Cc1cc2c3c(c1)N(c1cc4c(cc1C)C(C)(C)CCC4(C)C)c1cc4c(cc1B3c1ccc(C(C)C)cc1N2c1cc2c(cc1C)C(C)(C)CCC2(C)C)oc1cc2c(cc14)C(C)(C)CCC2(C)C ; Cc1cc2c(cc1N1c3ccc(C(C)C)cc3B3c4ccc5c(oc6ccccc65)c4N(c4cc5c(cc4C)C(C)(C)CCC5(C)C)c4cc(C(C)(C)C)cc1c43)C(C)(C)CCC2(C)C ; Cc1cc2c(cc1N1c3ccc(C(C)C)cc3B3c4cc5c(cc4N(c4cc6c(cc4C)C(C)(C)CCC6(C)C)c4cc(C(C)(C)C)cc1c43)oc1ccccc15)C(C)(C)CCC2(C)C]

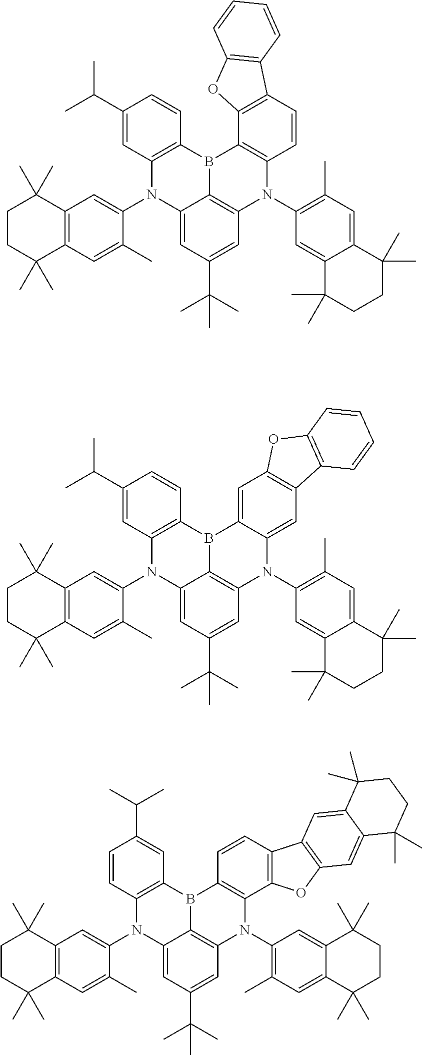 [SMILES: Cc1cc2c(cc1N1c3cc(C(C)C)ccc3B3c4c1cc(C(C)(C)C)cc4N(c1cc4c(cc1C)C(C)(C)CCC4(C)C)c1ccc4c(oc5ccccc54)c13)C(C)(C)CCC2(C)C ; Cc1cc2c(cc1N1c3cc(C(C)C)ccc3B3c4cc5oc6ccccc6c5cc4N(c4cc5c(cc4C)C(C)(C)CCC5(C)C)c4cc(C(C)(C)C)cc1c43)C(C)(C)CCC2(C)C ; Cc1cc2c(cc1N1c3ccc(C(C)C)cc3B3c4ccc5c(oc6cc7c(cc65)C(C)(C)CCC7(C)C)c4N(c4cc5c(cc4C)C(C)(C)CCC5(C)C)c4cc(C(C)(C)C)cc1c43)C(C)(C)CCC2(C)C]

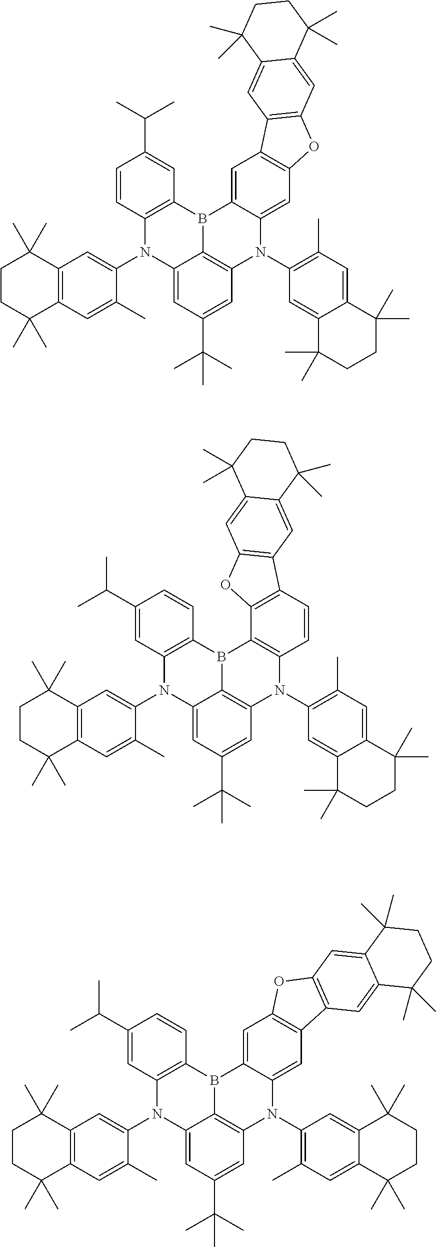 [SMILES: Cc1cc2c(cc1N1c3ccc(C(C)C)cc3B3c4cc5c(cc4N(c4cc6c(cc4C)C(C)(C)CCC6(C)C)c4cc(C(C)(C)C)cc1c43)oc1cc3c(cc15)C(C)(C)CCC3(C)C)C(C)(C)CCC2(C)C ; Cc1cc2c(cc1N1c3cc(C(C)C)ccc3B3c4c1cc(C(C)(C)C)cc4N(c1cc4c(cc1C)C(C)(C)CCC4(C)C)c1ccc4c(oc5cc6c(cc54)C(C)(C)CCC6(C)C)c13)C(C)(C)CCC2(C)C ; Cc1cc2c(cc1N1c3cc(C(C)C)ccc3B3c4cc5oc6cc7c(cc6c5cc4N(c4cc5c(cc4C)C(C)(C)CCC5(C)C)c4cc(C(C)(C)C)cc1c43)C(C)(C)CCC7(C)C)C(C)(C)CCC2(C)C]

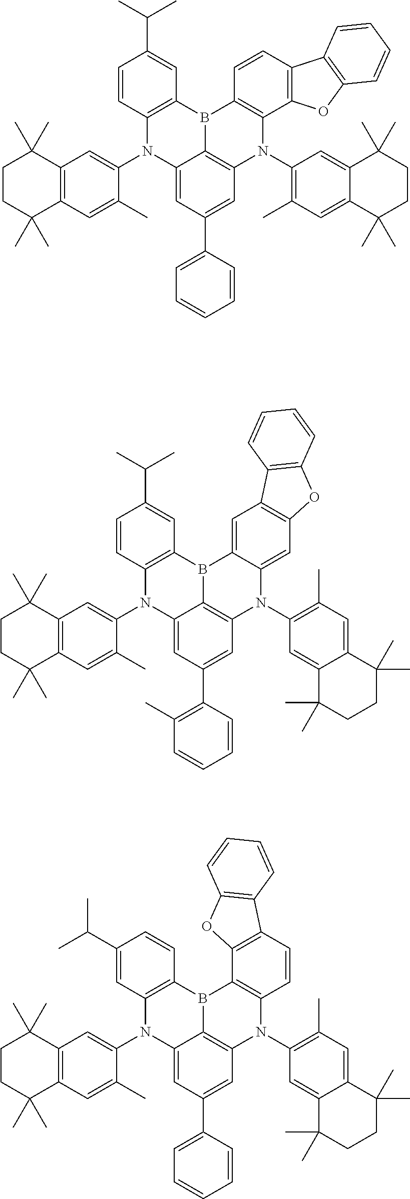 [SMILES: Cc1cc2c(cc1N1c3ccc(C(C)C)cc3B3c4ccc5c(oc6ccccc65)c4N(c4cc5c(cc4C)C(C)(C)CCC5(C)C)c4cc(-c5ccccc5)cc1c43)C(C)(C)CCC2(C)C ; Cc1ccccc1-c1cc2c3c(c1)N(c1cc4c(cc1C)C(C)(C)CCC4(C)C)c1cc4oc5ccccc5c4cc1B3c1cc(C(C)C)ccc1N2c1cc2c(cc1C)C(C)(C)CCC2(C)C ; Cc1cc2c(cc1N1c3cc(C(C)C)ccc3B3c4c1cc(-c1ccccc1)cc4N(c1cc4c(cc1C)C(C)(C)CCC4(C)C)c1ccc4c(oc5ccccc54)c13)C(C)(C)CCC2(C)C]

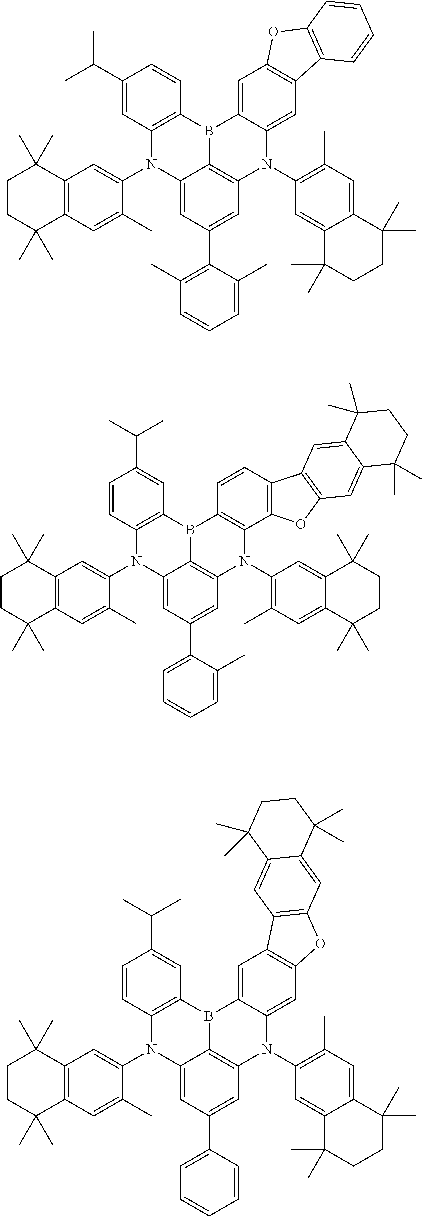 [SMILES: Cc1cc2c(cc1N1c3cc(C(C)C)ccc3B3c4cc5oc6ccccc6c5cc4N(c4cc5c(cc4C)C(C)(C)CCC5(C)C)c4cc(-c5c(C)cccc5C)cc1c43)C(C)(C)CCC2(C)C ; Cc1ccccc1-c1cc2c3c(c1)N(c1cc4c(cc1C)C(C)(C)CCC4(C)C)c1c(ccc4c1oc1cc5c(cc14)C(C)(C)CCC5(C)C)B3c1cc(C(C)C)ccc1N2c1cc2c(cc1C)C(C)(C)CCC2(C)C ; Cc1cc2c(cc1N1c3ccc(C(C)C)cc3B3c4cc5c(cc4N(c4cc6c(cc4C)C(C)(C)CCC6(C)C)c4cc(-c6ccccc6)cc1c43)oc1cc3c(cc15)C(C)(C)CCC3(C)C)C(C)(C)CCC2(C)C]

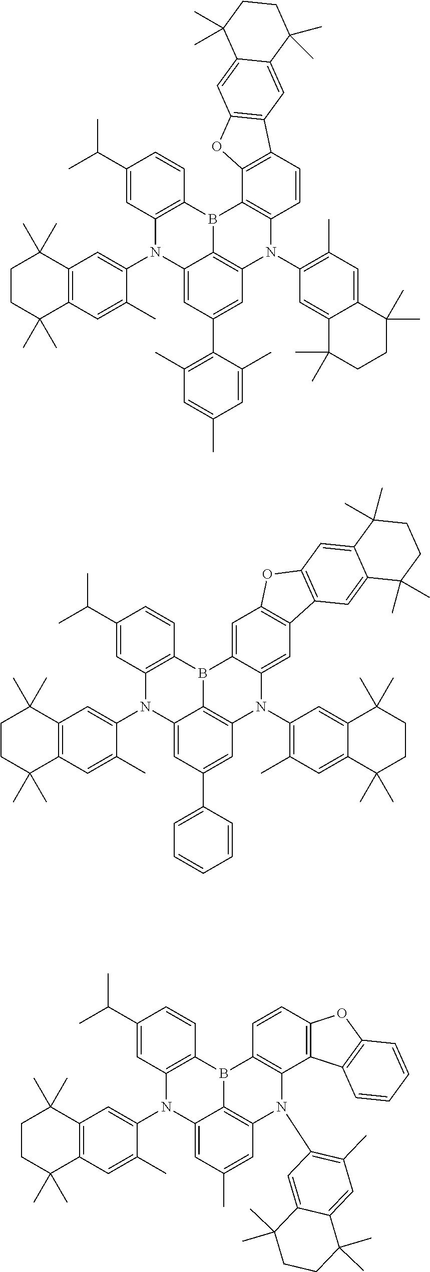 [SMILES: Cc1cc(C)c(-c2cc3c4c(c2)N(c2cc5c(cc2C)C(C)(C)CCC5(C)C)c2ccc5c(oc6cc7c(cc65)C(C)(C)CCC7(C)C)c2B4c2ccc(C(C)C)cc2N3c2cc3c(cc2C)C(C)(C)CCC3(C)C)c(C)c1 ; Cc1cc2c(cc1N1c3cc(C(C)C)ccc3B3c4cc5oc6cc7c(cc6c5cc4N(c4cc5c(cc4C)C(C)(C)CCC5(C)C)c4cc(-c5ccccc5)cc1c43)C(C)(C)CCC7(C)C)C(C)(C)CCC2(C)C ; Cc1cc2c3c(c1)N(c1cc4c(cc1C)C(C)(C)CCC4(C)C)c1c(ccc4oc5ccccc5c14)B3c1ccc(C(C)C)cc1N2c1cc2c(cc1C)C(C)(C)CCC2(C)C]

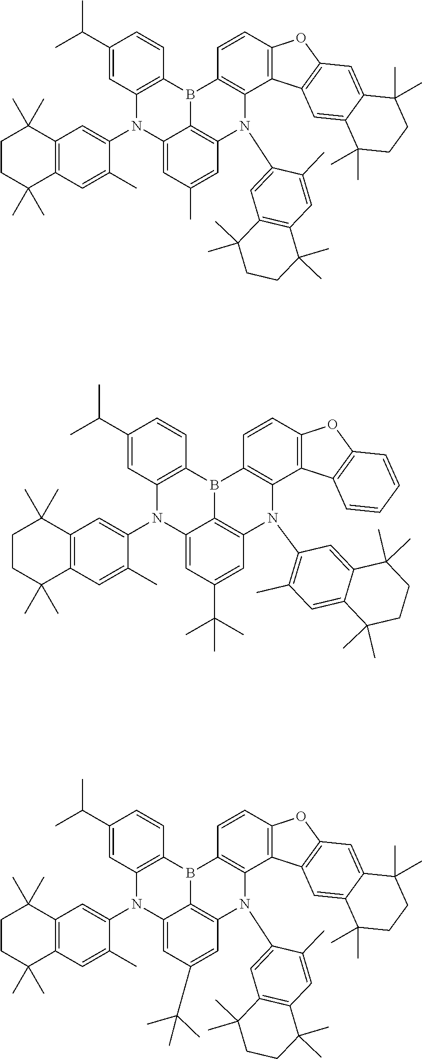 [SMILES: Cc1cc2c3c(c1)N(c1cc4c(cc1C)C(C)(C)CCC4(C)C)c1c(ccc4oc5cc6c(cc5c14)C(C)(C)CCC6(C)C)B3c1ccc(C(C)C)cc1N2c1cc2c(cc1C)C(C)(C)CCC2(C)C ; Cc1cc2c(cc1N1c3cc(C(C)C)ccc3B3c4ccc5oc6ccccc6c5c4N(c4cc5c(cc4C)C(C)(C)CCC5(C)C)c4cc(C(C)(C)C)cc1c43)C(C)(C)CCC2(C)C ; Cc1cc2c(cc1N1c3cc(C(C)C)ccc3B3c4ccc5oc6cc7c(cc6c5c4N(c4cc5c(cc4C)C(C)(C)CCC5(C)C)c4cc(C(C)(C)C)cc1c43)C(C)(C)CCC7(C)C)C(C)(C)CCC2(C)C]

8. An organic light emitting device comprising:
a first electrode;
a second electrode provided opposite to the first electrode; and
one or more organic material layers provided between the first electrode and the second electrode,
wherein one or more layers of the organic material layers include the polycyclic compound of claim 1.

9. The organic light emitting device of claim 8, wherein the organic material layer includes a light emitting layer, and the light emitting layer includes the polycyclic compound.

10. The organic light emitting device of claim 8, wherein the organic material layer includes a light emitting layer; and
the light emitting layer includes the polycyclic compound as a dopant of the light emitting layer, and includes a compound of the following Chemical Formula H as a host of the light emitting layer: 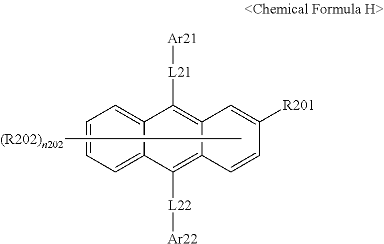
wherein in Chemical Formula H:
L21 and L22 are the same as or different from each other, and each independently is a direct bond, a substituted or unsubstituted arylene group, or a substituted or unsubstituted heteroarylene group;
Ar21 and Ar22 are the same as or different from each other, and each independently is a substituted or unsubstituted aryl group or a substituted or unsubstituted heterocyclic group;
R201 and R202 are the same as or different from each other, and each independently is hydrogen, deuterium, a halogen group, a substituted or unsubstituted alkyl group, a substituted or unsubstituted cycloalkyl group, a substituted or unsubstituted aryl group or a substituted or unsubstituted heterocyclic group; and
n202 is an integer of 0 to 7, and when n202 is 2 or greater, the R202s are the same as or different from each other.

11. The organic light emitting device of claim 8, wherein the organic material layer further includes one, two or more layers selected from the group consisting of a light emitting layer, a hole injection layer, a hole transfer layer, an electron injection layer, an electron transfer layer, an electron blocking layer and a hole blocking layer.
